(19) United States
(12) Patent Application Publication
(10) Pub. No.: US 2023/0112032 A1
(43) Pub. Date: Apr. 13, 2023

(54) COMPOSITION, LAYER INCLUDING THE COMPOSITION, LIGHT-EMITTING DEVICE INCLUDING THE COMPOSITION, AND ELECTRONIC APPARATUS INCLUDING THE LIGHT-EMITTING DEVICE

(71) Applicant: Samsung Electronics Co., Ltd., Suwon-si (KR)

(72) Inventors: Myungsun Sim, Suwon-si (KR); Seungyeon Kwak, Suwon-si (KR); Sungmin Kim, Incheon (KR); Hyungjun Kim, Suwon-si (KR); Banglin Lee, Suwon-si (KR); Sunghun Lee, Hwaseong-si (KR); Yong Joo Lee, Suwon-si (KR); Byoungki Choi, Hwaseong-si (KR)

(21) Appl. No.: 17/836,434

(22) Filed: Jun. 9, 2022

(30) Foreign Application Priority Data
Jun. 11, 2021 (KR) 10-2021-0076311

(51) Int. Cl. H01L 51/00; C07F 15/00; C09K 11/06

(52) U.S. Cl. CPC H01L 51/0085; C07F 15/0033; C09K 11/06; H01L 51/0094; H01L 2251/552; H01L 51/5012

(57) ABSTRACT

A composition including a first compound and a second compound, wherein the first compound is an organometallic compound represented by Formula 1, the second compound is an organometallic compound represented by Formula 2, the first compound and the second compound are different from each other, the first compound and the second compound are each not tris[2-phenylpyridine]iridium, and |λP(Ir1)-λP(Ir2)| is in a range of 0 nm to about 30 nm, and at least one of Expressions 1 to 4 presented in the specification is satisfied,

Ir(L₁₁)ₙ₁₁(L₁₂)ₙ₁₂(L₁₃)ₙ₁₃ Formula 1

Ir(L₂₁)ₙ₂₁(L₂₂)ₙ₂₂(L₂₃)ₙ₂₃ Formula 2

wherein
L₁₁ to L₁₃, L₂₁ to L₂₃, n11 to n13, and n21 to n23 are as provided herein.

### CROSS-REFERENCE TO RELATED APPLICATION

This application is based on and claims priority to Korean Patent Application No. 10-2021-0076311, filed on Jun. 11, 2021, in the Korean Intellectual Property Office, and all benefits accruing therefrom under 35 U.S.C. § 119, the content of which is incorporated by reference herein in its entirety.

### BACKGROUND

### 1. Field

One or more embodiments relate to a composition, a layer including the composition, a light-emitting device including the composition, and an electronic apparatus including the light-emitting device.

### 2. Description of the Related Art

From among light-emitting devices, organic light-emitting devices (OLEDs) are self-emissive devices, which have improved characteristics in terms of viewing angles, response time, luminance, driving voltage, and response speed, and produce full-color images.

In an example, an OLED may include an anode, a cathode, and an organic layer located between the anode and the cathode, wherein the organic layer includes an emission layer. A hole transport region may be located between the anode and the emission layer, and an electron transport region may be located between the emission layer and the cathode. Holes injected from the anode may move toward the emission layer through the hole transport region, and electrons injected from the cathode may move toward the emission layer through the electron transport region. The holes and the electrons recombine in the emission layer to produce excitons. These excitons transition from an excited state to a ground state, thereby generating light.

### SUMMARY

Provided are a composition capable of providing excellent luminescence efficiency and the like, a layer including the composition, a light-emitting device including the composition, and an electronic apparatus including the light-emitting device.

Additional aspects will be set forth in part in the description, which follows and, in part, will be apparent from the description, or may be learned by practice of the presented embodiments of the disclosure.

According an aspect, provided is a composition including

a first compound and a second compound, wherein

the first compound is an organometallic compound represented by Formula 1,

the second compound is an organometallic compound represented by Formula 2,

the first compound and the second compound are different from each other,

the first compound and the second compound are each not tris[2-phenylpyridine]iridium,

|λP(Ir1)-λP(Ir2)| is in a range of 0 nanometers (nm) to about 30 nm, and

at least one of Expressions 1 to 4 is satisfied:

λP(Ir1)>λP(Ir2) Expression 1

PLQY(Ir1)>PLQY(Ir2) Expression 2

kᵣ(Ir1)>kᵣ(Ir2) Expression 3

HOR(Ir1)>HOR(Ir2) Expression 4

wherein, in |λP(Ir1)-λP(Ir2)| and Expressions 1 to 4,

λP(Ir1) indicates an emission peak wavelength of the first compound,

λP(Ir2) indicates an emission peak wavelength of the second compound,

λP(Ir1) and λP(Ir2) are evaluated from photoluminescence spectra measured for each of a first film and a second film,

PLQY(Ir1) indicates a photoluminescence quantum yield of the first compound,

PLQY(Ir2) indicates a photoluminescence quantum yield of the second compound,

PLQY(Ir1) and PLQY(Ir2) are measured for each of the first film and the second film,

kᵣ(Ir1) indicates a radiative decay rate of the first compound,

kᵣ(Ir2) indicates a radiative decay rate of the second compound,

kᵣ(Ir1) and kᵣ(Ir2) are evaluated from photoluminescence spectra and time-resolved photoluminescence spectra measured for each of the first film and the second film,

HOR(Ir1) indicates a horizontal orientation ratio of the first compound,

HOR(Ir2) indicates a horizontal orientation ratio of the second compound, and

HOR(Ir1) and HOR(Ir2) are evaluated from emission intensity measured for each of the first film and the second film,

wherein the first film is a film including the first compound, and

the second film is a film including the second compound,

Ir(L₁₁)ₙ₁₁(L₁₂)ₙ₁₂(L₁₃)ₙ₁₃ Formula 1

Ir(L₂₁)ₙ₂₁(L₂₂)ₙ₂₂(L₂₃)ₙ₂₃ Formula 2

wherein, in Formulae 1 and 2,

L₁₁ and L₂₁ are each independently:
a bidentate ligand bonded to iridium (Ir) of Formula 1 or Formula 2 via two nitrogen atoms;
a bidentate ligand bonded to Ir of Formula 1 or Formula 2 via a nitrogen atom and a carbon atom; or
a bidentate ligand bonded to Ir of Formula 1 or Formula 2 via two carbon atoms,

L₁₂, L₁₃, L₂₂, and L₂₃ are each independently:

a bidentate ligand bonded to Ir of Formula 1 or Formula 2 via two nitrogen atoms,

a bidentate ligand bonded to Ir of Formula 1 or Formula 2 via a nitrogen atom and a carbon atom;

a bidentate ligand bonded to Ir of Formula 1 or Formula 2 via two carbon atoms; or

a bidentate ligand bonded to Ir of Formula 1 or Formula 2 via two oxygen atoms,

n11 and n12 may each independently be 1 or 2,

n13 may be 0 or 1,
the sum of n11, n12, and n13 may be 3,

n21 and n22 are each independently 1 or 2,

n23 is 0 or 1, and

the sum of n21, n22, and n23 is 3,

wherein Condition 1 is satisfied:

Condition 1

when a) L₁₁ is a bidentate ligand bonded to Ir of Formula 1 via a nitrogen atom and a carbon atom; b) L₁₁ includes ring A₁ bonded to Ir of Formula 1 via a nitrogen atom, and ring A₂ bonded to Ir of Formula 1 via a carbon atom; c) L₂₁ is a bidentate ligand bonded to Ir of Formula 2 via a nitrogen atom and a carbon atom; d) L₂₁ includes ring A₅ bonded to Ir of Formula 2 via a nitrogen atom, and ring A₆ bonded to Ir of Formula 2 via a carbon atom; e) L₁₂ and L₂₂ are each a bidentate ligand bonded to Ir of Formula 1 or Formula 2 via two oxygen atoms; f) n11 and n21 are each 2; and g) n12 and n22 are each 1, ring A₁ and ring A₅ are different from each other.

According to another aspect, provided is a layer including the composition.

According to another aspect, provided is a light-emitting device including: a first electrode; a second electrode; and an organic layer located between the first electrode and the second electrode and including an emission layer, wherein the organic layer further includes the composition.

For example, the emission layer in the organic layer of the light-emitting device may include the composition.

According to another aspect, provided is an electronic apparatus including the light-emitting device.

### BRIEF DESCRIPTION OF THE DRAWING

The above and other aspects, features, and advantages of certain embodiments of the disclosure will be more apparent from the following description taken in conjunction with

FIGURE which shows a schematic cross-sectional view of an organic light-emitting device according to an embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

According to an aspect, provided is a composition including a first compound and a second compound.

The first compound is an organometallic compound represented by Formula 1, and the second compound is an organometallic compound represented by Formula 2:

Ir(L₁₁)ₙ₁₁(L₁₂)ₙ₁₂(L₁₃)ₙ₁₃ Formula 1

Ir(L₂₁)ₙ₂₁(L₂₂)ₙ₂₂(L₂₃)ₙ₂₃ Formula 2

wherein, Formulae 1 and 2 each include one iridium (Ir).

The detailed descriptions of the Formulae 1 and 2 are described herein in further detail.

The first compound and the second compound are different from each other.

The first compound and the second compound are not each tris[2-phenylpyridine]iridium (see the first compound of Group B). In other words, neither the first compound nor the second compound is tris[2-phenylpyridine]iridium.

In an embodiment, the first compound and the second compound may not each be a compound of Group B, wherein R′ and R″ are each independently a C₁ to C₂₀ alkyl group, and R is hydrogen, F or Cl:

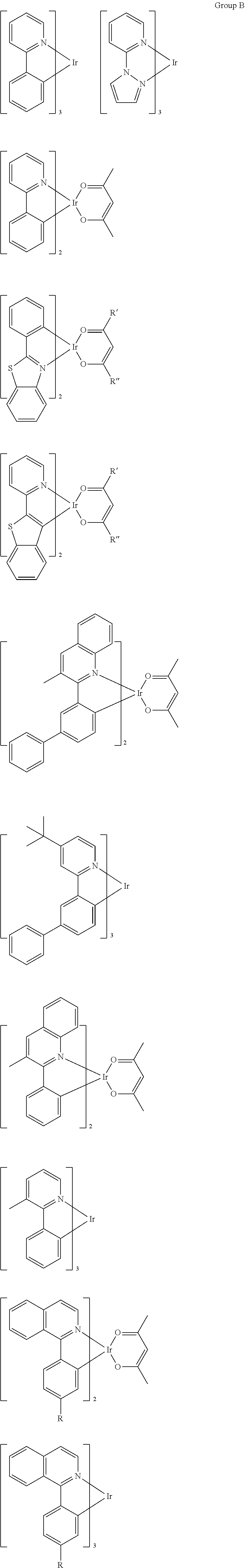

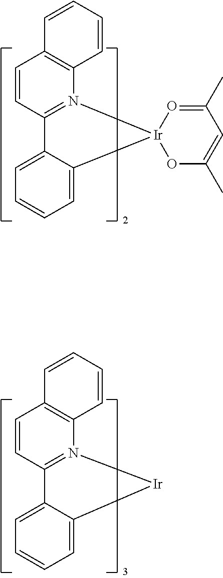

In an embodiment, the first compound and the second compound may each be electrically neutral.

In one or more embodiments, at least one of the first compound and the second compound may be a heteroleptic compound.

In one or more embodiments, the first compound and the second compound may each be a heteroleptic compound.

A first film may be a film including the first compound. For example, the first film including the first compound may have an emission peak wavelength evaluated from photoluminescence spectra, a photoluminescence quantum yield, a radiative decay rate evaluated from photoluminescence spectra and time-resolved photoluminescence spectra, and a horizontal orientation ratio evaluated from the emission intensity (for example, at each angle). For example, the first film may be a film having a thickness of 40 nanometers that is obtained by vacuum depositing the first compound on a quartz substrate. As used herein, the term “emission peak wavelength” refer to a wavelength in the emission peak at which the emission intensity is maximum.

A second film may be a film including the second compound. For example, the second film including the second compound may have an emission peak wavelength evaluated from photoluminescence spectra, a photoluminescence quantum yield, a radiative decay rate evaluated from photoluminescence spectra and time-resolved photoluminescence spectra, and a horizontal orientation ratio evaluated from the emission intensity (for example, at each angle). For example, the second film may be a film having a thickness of 40 nanometers that is obtained by vacuum depositing the second compound on a quartz substrate.

|λP(Ir1)-λP(Ir2)| of the composition is in a range of 0 nm to about 30 nm, wherein |λP(Ir1)-λP(Ir2)| indicates an absolute value of λP(Ir1)-λP(Ir2), and the composition satisfies at least one of Expressions 1 to 4:

λP(Ir1)>λP(Ir2) Expression 1

PLQY(Ir1)>PLQY(Ir2) Expression 2

kᵣ(Ir1)>kᵣ(Ir2) Expression 3

HOR(Ir1)>HOR(Ir2) Expression 4

In |λP(Ir1)-λP(Ir2)| and Expression 1, λP(Ir1) indicates the emission peak wavelength of the first compound, and λP(Ir2) indicates the emission peak wavelength of the second compound.

λP(Ir1) and λP(Ir2) are evaluated from photoluminescence spectra measured for each of a first film corresponding to λP(Ir1) and a second film corresponding to λP(Ir2). For example, evaluation methods of λP(Ir1) and λP(Ir2) may be as described in Evaluation Example 1 below.

In Expression 2, PLQY(Ir1) indicates the photoluminescence quantum yield of the first compound, and PLQY(Ir2) indicates the photoluminescence quantum yield of the second compound.

PLQY(Ir1) and PLQY(Ir2) are measured for each of the first film and the second film. For example, evaluation methods of PLQY(Ir1) and PLQY(Ir2) may be as described in Evaluation Example 1 hereinbelow.

In Expression 3, kᵣ(Ir1) indicates the radiative decay rate of the first compound, and kᵣ(Ir2) indicates the radiative decay rate of the second compound.

kᵣ(Ir1) and kᵣ(Ir2) are evaluated from photoluminescence spectra and time-resolved photoluminescence spectra measured for each of the first film corresponding to kᵣ(Ir1) and the second film corresponding to kᵣ(Ir2). For example, evaluation methods of kᵣ(Ir1) and kᵣ(Ir2) may be as described in Evaluation Example 2 below.

In Expression 4, HOR(Ir1) indicates the horizontal orientation ratio of the first compound, and HOR(Ir2) indicates a horizontal orientation ratio of the second compound.

HOR(Ir1) and HOR(Ir2) are evaluated from emission intensity at each angle measured for each of the first film corresponding to HOR(Ir1) and the second film corresponding to HOR(Ir2). For example, evaluation methods of HOR(Ir1) and HOR(Ir2) may be as described in Evaluation Example 3 below.

The term “first film” as used herein refers to a film including the first compound, and the term “second film” as used herein refers to a film including the second compound. The first film and the second film may be manufactured using any suitable method, for example, various methods such as a vacuum deposition method, a coating and heating method, or the like. The first film and the second film may each further include a compound, for example, a host as described herein, other than the first compound and the second compound. In other words, each of the first and/or the second film independently may include an additional compound.

L₁₁ and L₂₁ in Formulae 1 and 2 are each independently:

a bidentate ligand bonded to Ir of Formula 1 or Formula 2 via two nitrogen atoms,

a bidentate ligand bonded to Ir of Formula 1 or Formula 2 via a nitrogen atom and a carbon atom; or a bidentate ligand bonded to Ir of Formula 1 or Formula 2 via two carbon atoms.

In an embodiment, L₁₁ and L₂₁ may each be a bidentate ligand bonded to Ir of Formula 1 or Formula 2 via a nitrogen atom and a carbon atom.

L₁₂, L₁₃, L₂₂, and L₂₃ in Formulae 1 and Formula 2 are each independently:

a bidentate ligand bonded to Ir of Formula 1 or Formula 2 via two nitrogen atoms;

a bidentate ligand bonded to Ir of Formula 1 or Formula 2 via a nitrogen atom and a carbon atom;

a bidentate ligand bonded to Ir of Formula 1 or Formula 2 via two carbon atoms; or

a bidentate ligand bonded to Ir of Formula 1 or Formula 2 via two oxygen atoms.

In an embodiment, L₁₂, L₁₃, L₂₂, and L₂₃ may each independently be:

a bidentate ligand bonded to Ir of Formula 1 or Formula 2 via a nitrogen atom and a carbon atom; or

a bidentate ligand bonded to Ir of Formula 1 or Formula 2 via two oxygen atoms.

In Formula 1, n11 and n12 are each independently 1 or 2, n13 is 0 or 1, and the sum of n11, n12, and n13 is 3.

In an embodiment, in Formula 1, i) n11 may be 1, n12 may be 2, and n13 may be 0; or ii) n11 may be 2, n12 may be 1, and n13 may be 0.

In one or more embodiments, in Formula 1,

L₁₁ and L₁₂ may be different from each other,

i) n11 may be 1, n12 may be 2, and n13 may be 0; or ii) n11 may be 2, n12 may be 1, and n13 may be 0.

In Formula 2, n21 and n22 may each independently be 1 or 2, n23 may be 0 or 1, and the sum of n21, n22, and n23 may be 3.

In an embodiment, in Formula 2, i) n21 may be 1, n22 may be 2, and n23 may be 0; or ii) n21 may be 2, n22 may be 1, and n23 may be 0.

In one or more embodiments, in Formula 2,

L₂₁ and L₂₂ may be different from each other,

i) n21 may be 1, n22 may be 2, and n23 may be 0; or ii) n21 may be 2, n22 may be 1, and n23 may be 0.

Formulae 1 and Formula 2 satisfy Condition 1:

Condition 1

when a) L₁₁ is a bidentate ligand bonded to Ir of Formula 1 via a nitrogen atom and a carbon atom; b) L₁₁ includes ring A₁ bonded to Ir of Formula 1 via a nitrogen atom, and ring A₂ bonded to Ir of Formula 1 via a carbon atom; c) L₂₁ is a bidentate ligand bonded to Ir of Formula 2 via a nitrogen atom and a carbon atom; d) L₂₁ includes ring A₅ bonded to Ir of Formula 2 via a nitrogen atom, and ring A₆ bonded to Ir of Formula 2 via a carbon atom; e) L₁₂ and L₂₂ are each a bidentate ligand bonded to Ir of Formula 1 or Formula 2 via two oxygen atoms; f) n11 and n21 are each 2; and g) n12 and n22 are each 1, ring A₁ and ring A₅ are different from each other. That is, when all of “a)” to “f)” described above are true, ring A₁ and ring A₅ are different from each other.

An electronic device, for example, a light-emitting device, using the composition as described above, wherein i) |λP(Ir1)-λP(Ir2)| is in a range of 0 nm to about 30 nm, ii) at least one of Expressions 1 to 4 is satisfied, and iii) Condition 1 is satisfied, may emit red light, yellowish-green light, green light, or blue light, or other colors than white light, and may have an excellent driving voltage, excellent external quantum efficiency, and excellent lifespan characteristics.

In an embodiment, |λP(Ir1)-λP(Ir2)| of the composition may be in a range of 0 nm to about 25 nm, 0 nm to about 20 nm, about 2 nm to about 25 nm, about 2 nm to about 20 nm, about 4 nm to about 25 nm, or about 4 nm to about 20 nm.

In one or more embodiments, the composition may not emit white light.

In one or more embodiments, the composition may emit red light (for example, light having an emission peak wavelength in a range of about 570 nm to about 650 nm), yellowish-green light (for example, light having an emission peak wavelength in a range of about 540 nm to about 570 nm), green light (for example, light having an emission peak wavelength in a range of about 500 nm to about 540 nm), or blue light (for example, light having an emission peak wavelength in a range of about 400 nm to about 500 nm).

In one or more embodiments, the composition may emit green light (for example, light having an emission peak wavelength in a range of about 500 nm to about 540 nm) or yellowish-green light (for example, light having an emission peak wavelength in a range of about 540 nm to about 570 nm), and |λP(Ir1)-λP(Ir2)| of the composition may be in a range of 0 nm to about 20 nm, 0 nm to about 10 nm, about 2 nm to about 20 nm, about 2 nm to about 10 nm, about 4 nm to about 20 nm, or about 4 nm to about 10 nm.

In one or more embodiments, the composition may emit red light (for example, light having an emission peak wavelength in a range of about 570 nm to about 650 nm), and |λP(Ir1)-λP(Ir2)| of the composition may be in a range of about 5 nm to about 25 nm, about 5 nm to about 20 nm, or about 7 nm to about 20 nm.

In one or more embodiments, the composition may emit blue light (for example, light having an emission peak wavelength in a range of about 400 nm to about 500 nm), and |λP(Ir1)-λP(Ir2)| of the composition may be in a range of about 2 nm to about 25 nm, or about 5 nm to about 20 nm.

In one or more embodiments, the composition may satisfy Expression 1.

In one or more embodiments, the composition may satisfy at least one of Expressions 2 to 4.

In one or more embodiments, the composition may satisfy 1) Expression 1; and 2) at least one of Expressions 2 to 4.

In one or more embodiments, the composition may satisfy all of Expressions 1 to 4.

In one or more embodiments, the composition may satisfy at least one of Expressions 1 to 4, and the composition may further satisfy Expression 5:

HOMO(Ir1)<HOMO(Ir2) Expression 5

wherein, in Expression 5,

HOMO(Ir1) indicates a highest occupied molecular orbital (HOMO) energy level of the first compound,

HOMO(Ir2) indicates a HOMO energy level of the second compound, and

HOMO(Ir1) and HOMO(Ir2) may each be a negative value (in electron volts, eV) measured by using a photoelectron spectrometer under atmospheric pressure.

For example, HOMO(Ir1) and HOMO(Ir2) may each be a negative value measured by using a photoelectron spectrometer, e.g., AC3 manufactured by RIKEN KEIKI Co., Ltd. (see Evaluation Example 4 below), under atmospheric pressure.

Since the composition further satisfies Expression 5, the second compound in the composition may have a shallower HOMO energy level than the HOMO energy level of the first compound, and thus, a relatively larger quantity of holes may be trapped in the second compound. Thus, in an electronic device, for example, a light-emitting device, using the composition, holes and electrons may effectively recombine in the first compound and/or the second compound without the first compound and the second compound changing into an anionic state due to electrons being injected into the composition, and without an increase in driving voltage, and thus, excellent luminescence efficiency and excellent lifespan characteristics may be obtained.

In one or more embodiments, |HOMO(Ir1)-HOMO(Ir2)| of the composition may be in a range of about 0.02 eV to about 0.30 eV, about 0.03 eV to about 0.20 eV, or about 0.03 eV to about 0.10 eV.

|HOMO(Ir1)-HOMO(Ir2)| indicates an absolute value of HOMO(Ir1)-HOMO(Ir2).

In one or more embodiments, λP(Ir1) and λP(Ir2) may each be in a range of about 500 nm to about 570 nm.

In one or more embodiments, the composition may satisfy Expression 1, and
i) λP(Ir1) may be in a range of about 520 nm to about 540 nm, and λP(Ir2) may be in a range of about 500 nm to about 530 nm, or
ii) λP(Ir1) may be in a range of about 550 nm to about 570 nm, and λP(Ir2) may be in a range of about 540 nm to about 560 nm.

In one or more embodiments, λP(Ir1) and λP(Ir2) may each be in a range of about 500 nm to about 570 nm, and L₁₁, L₁₂, L₁₃, L₂₁, L₂₂, and L₂₃ in Formulae 1 and 2 may each be a bidentate ligand bonded to Ir of Formula 1 or Formula 2 via a nitrogen atom and a carbon atom.

In one or more embodiments, λP(Ir1) and λP(Ir2) may each be in a range of about 570 nm to about 650 nm.

In one or more embodiments, the composition may satisfy Expression 1, λP(Ir1) may be in a range of about 620 nm to about 650 nm, and λP(Ir2) may be in a range of about 570 nm to about 630 nm.

In one or more embodiments, i) λP(Ir1) and λP(Ir2) may each be in a range of about 570 nm to about 650 nm, and ii) in Formulae 1 and Formula 2, L₁₁, L₁₃, L₂₁, and L₂₃ may each be a bidentate ligand bonded to Ir of Formula 1 or Formula 2 via a nitrogen atom and a carbon atom, L₁₂ and L₂₂ may each be a bidentate ligand bonded to Ir of Formula 1 or Formula 2 via two oxygen atoms, and n12 and n22 may each be 1.

In one or more embodiments, i) λP(Ir1) and λP(Ir2) may each be in a range of about 570 nm to about 650 nm, ii) in Formulae 1 and 2, L₁₁, L₁₃, L₂₁, and L₂₃ may each be a bidentate ligand bonded to Ir of Formula 1 or Formula 2 via a nitrogen atom and a carbon atom, L₁₂ and L₂₂ may each be a bidentate ligand bonded to Ir of Formula 1 or Formula 2 via two oxygen atoms, and n12 and n22 may each be 1, and iii) L₁₁ may include ring A₁ bonded to Ir of Formula 1 via a nitrogen atom, L₂₁ may include ring A₅ bonded to Ir of Formula 2 via a nitrogen atom, and at least one of ring A₁ and ring A₅ may not be pyridine.

In one or more embodiments, i) λP(Ir1) and λP(Ir2) may each be in a range of about 570 nm to about 650 nm, ii) in Formulae 1 and 2, L₁₁, L₁₃, L₂₁, and L₂₃ may each be a bidentate ligand bonded to Ir of Formula 1 or Formula 2 via a nitrogen atom and a carbon atom, L₁₂ and L₂₂ may each be a bidentate ligand bonded to Ir of Formula 1 or Formula 2 via two oxygen atoms, and n12 and n22 may each be 1, and iii) L₁₁ may include ring A₁ bonded to Ir of Formula 1 via a nitrogen atom, L₂₁ may include ring A₅ bonded to Ir of Formula 2 via a nitrogen atom, and ring A₁ and ring A₅ may each be a polycyclic group having 4 to 60 carbon atoms (for example, 4 to 30 carbon atoms) (for example, a quinoline group, an isoquinoline group, a quinoxaline group, a quinazoline group, a benzoquinoline group, a benzoisoquinoline group, a benzoquinoxaline group, a benzoquinazoline group, a phenanthroline group, or a phenanthridine group).

In one or more embodiments, λP(Ir1) and λP(Ir2) may each be in a range of about 400 nm to about 500 nm.

In one or more embodiments, the composition may satisfy Expression 1, λP(Ir1) may be in a range of about 470 nm to about 500 nm, and λP(Ir2) may be in a range of about 430 nm to about 480 nm.

In one or more embodiments, HOR(Ir1) and HOR(Ir2) may each be in a range of about 75% to about 100%, for example, about 77% to about 95%, or about 80% to about 100%.

In one or more embodiments, the composition may satisfy at least one of Conditions A to D:

Condition A
L₁₁ and L₁₂ of Formula 1 are different from each other

Condition B
L₂₁ and L₂₂ of Formula 2 are different from each other

Condition C
L₁₁ of Formula 1 and L₂₁ of Formula 2 are different from each other

Condition D
L₁₂ of Formula 1 and L₂₂ of Formula 2 are different from each other.

In one or more embodiments, in Formulae 1 and 2,

L₁₁ may be a ligand represented by Formula 1-1,

L₁₂ may be a ligand represented by Formula 1-2 or 1-3,

L₁₃ may be a ligand represented by Formula 1-1, 1-2, or 1-3,

L₂₁ may be a ligand represented by Formula 2-1,

L₂₂ may be a ligand represented by Formula 2-2 or 2-3, and

L₂₃ may be a ligand represented by Formula 2-1, 2-2, or 2-3:

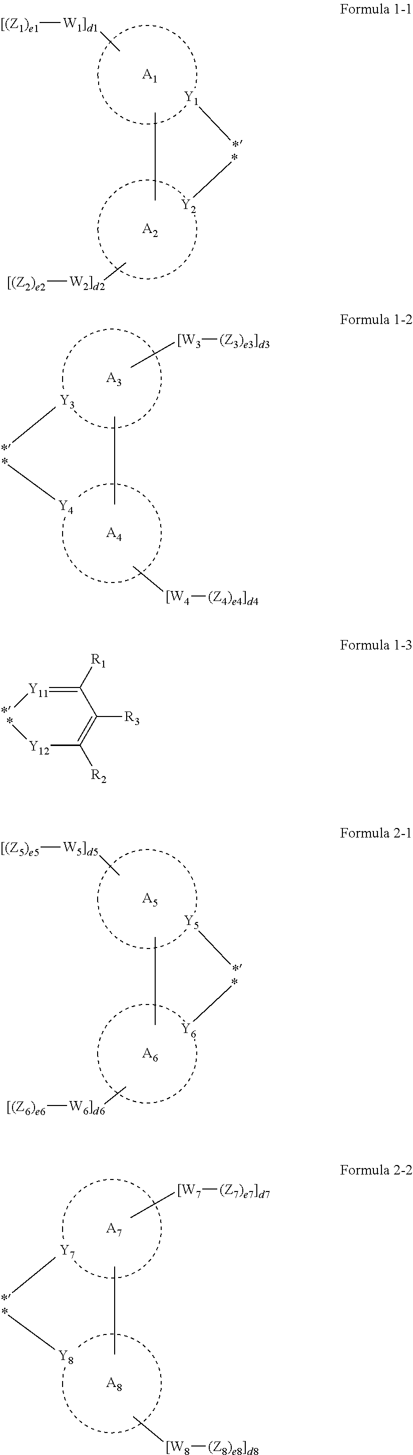

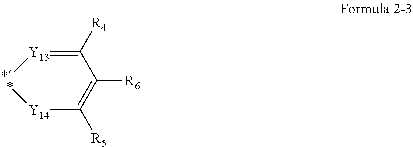

wherein, in Formulae 1-1 to 1-3 and 2-1 to 2-3, Y₁ to Y₈ may each independently be C or N, Y₁₁ to Y₁₄ may each be O, and * and *′ each represent a binding site to Ir.

In an embodiment, Y₁, Y₃, Y₅, and Y₇ may each be N, and Y₂, Y₄, Y₆, and Y₈ may each be C.

In one or more embodiments, i) Y₁ and Y₂ may each be C, ii) Y₃ and Y₄ may each be C, iii) Y₅ and Y₆ may each be C, or iv) Y₇ and Y₈ may each be C.

In one or more embodiments, in Formulae 1, 2, 1-1, 1-2, 2-1, and 2-2, i) a bond between Y₁ and Ir, a bond between Y₃ and Ir, a bond between Y₅ and Ir, and a bond between Y₇ and Ir may each be a coordinate bond, and ii) a bond between Y₂ and Ir, a bond between Y₄ and Ir, a bond between Y₆ and Ir, and a bond between Y₈ and Ir may each be a covalent bond.

Ring A₁ to ring A₈ in Formulae 1-1, 1-2, 2-1, and 2-2 may each independently be a C₅-C₃₀ carbocyclic group or a C₁-C₃₀ heterocyclic group.

In an embodiment, i) ring A₁, ring A₃, ring A₅, and ring A₇ may each be a C₁-C₃₀ heterocyclic group, and ii) ring A₂, ring A₄, ring A₆, and ring A₈ may each independently be a C₅-C₃₀ carbocyclic group or a C₁-C₃₀ heterocyclic group.

In one or more embodiments, i) ring A₁, ring A₃, ring A₅, and ring A₇ may each be a C₁-C₃₀ heterocyclic group, ii) ring A₂, ring A₄, ring A₆, and ring A₈ may each independently be a C₅-C₃₀ carbocyclic group or a C₁-C₃₀ heterocyclic group, iii) Y₁, Y₃, Y₅, and Y₇ may each be N, and iv) Y₂, Y₄, Y₆, and Y₈ may each be C.

In one or more embodiments, ring A₁, ring A₃, ring A₅, and ring A₇ in Formulae 1-1, 1-2, 2-1, and 2-2 may each independently be i) ring T1, ii) a condensed ring in which two or more ring T1 (s) are condensed with each other, or iii) a condensed ring in which at least one ring T1 and at least one ring T2 are condensed with each other, ring T1 may be a pyridine group, a pyrimidine group, a pyrazine group, a pyridazine group, a triazine group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

ring T2 may be a cyclopentane group, a cyclopentene group, a furan group, a thiophene group, a pyrrole group, a silole group, a borole group, a phosphole group, a germole group, a selenophene group, an adamantane group, a norbornane group, a norbornene group, a cyclohexane group, a cyclohexene group, or a benzene group.

In one or more embodiments, in Formulae 1-1, 1-2, 2-1, and 2-2, ring A₂, ring A₄, ring A₆, and ring A₈ may each independently be i) a first ring, ii) a second ring, iii) a condensed ring in which two or more first rings are condensed with each other, iv) a condensed ring in which two or more second rings are condensed with each other, or v) a condensed ring in which at least one first ring and at least one second ring are condensed with each other,

the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In an embodiment, ring A₁, ring A₃, ring A₅, and ring A₇ in Formulae 1-1, 1-2, 2-1, and 2-2 may each independently be an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, an imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a naphthopyrrole group, a naphthopyrazole group, a naphthoimidazole group, a naphthooxazole group, a naphthoisoxazole group, a naphthothiazole group, a naphthoisothiazole group, a naphthooxadiazole group, a naphthothiadiazole group, a phenanthrenopyrrole group, a phenanthrenopyrazole group, a phenanthrenoimidazole group, a phenanthrenooxazole group, a phenanthrenoisoxazole group, a phenanthrenothiazole group, a phenanthrenoisothiazole group, a phenanthrenooxadiazole group, a phenanthrenothiadiazole group, a 5,6,7,8-tetrahydroisoquinoline group, a 5,6,7,8-tetrahydroquinoline group, a pyridine group condensed with a cyclohexane group, or a pyridine group condensed with a norbornane group.

In one or more embodiments, ring A₂, ring A₄, ring A₆, and ring A₈ in Formulae 1-1, 1-2, 2-1, and 2-2 may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, an imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a naphthopyrrole group, a naphthopyrazole group, a naphthoimidazole group, a naphthooxazole group, a naphthoisoxazole group, a naphthothiazole group, a naphthoisothiazole group, a naphthooxadiazole group, a naphthothiadiazole group, a phenanthrenopyrrole group, a phenanthrenopyrazole group, a phenanthrenoimidazole group, a phenanthrenooxazole group, a phenanthrenoisoxazole group, a phenanthrenothiazole group, a phenanthrenoisothiazole group, a phenanthrenooxadiazole group, a phenanthrenothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

W₁ to W₈ in Formulae 1-1, 1-2, 2-1, and 2-2 may each independently be a single bond, a C₁-C₂₀ alkylene group unsubstituted or substituted with at least one R₁₀ₐ, a C₅-C₃₀ carbocyclic group unsubstituted or substituted with at least one R₁₀ₐ, or a C₁-C₃₀ heterocyclic group unsubstituted or substituted with at least one R₁₀ₐ.

In an embodiment, W₁ to W₈ in Formulae 1-1, 1-2, 2-1, and 2-2 may each independently be:
a single bond; or
a C₁-C₂₀ alkylene group, a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group, each unsubstituted or substituted with at least one R₁₀ₐ.

In an embodiment, W₁ to W₈ in Formulae 1-1, 1-2, 2-1, and 2-2 may each independently be:
a single bond; or
a benzene group, a naphthalene group, a pyridine group, a fluorene group, a carbazole group, a dibenzofuran group, or a dibenzothiophene group, each unsubstituted or substituted with at least one R₁₀ₐ.

In one or more embodiments, W₁ to W₈ in Formulae 1-1, 1-2, 2-1, and 2-2 may each independently be:
a single bond; or
a C₁-C₂₀ alkylene group, a benzene group, a naphthalene group, a dibenzofuran group, or a dibenzothiophene group, each unsubstituted or substituted with at least one of deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

Z₁ to Z₈ and R₁ to R₆ in Formulae 1-1, 1-2, 1-3, 2-1, 2-2, and 2-3 may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ are as described herein.

In an embodiment, Z₁ to Z₈ and R₁ to R₆ in Formulae 1-1, 1-2, 1-3, 2-1, 2-2, and 2-3 may each independently be:
hydrogen, deuterium, —F, —C₁, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₂-C₂₀ alkenyl group, a C₁-C₂₀ alkoxy group, or a C₁-C₂₀ alkylthio group; a C₁-C₂₀ alkyl group, a C₂-C₂₀ alkenyl group, a C₁-C₂₀ alkoxy group, or a C₁-C₂₀ alkylthio group, each substituted with at least one of deuterium, —F, —C₁, —Br, —I, −CD₃, −CD₂H, −CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group (also referred to as a bicyclo[2.2.1]heptyl group), a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with at least one of deuterium, —F, —C₁, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a deuterated phenyl group, a fluorinated phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

wherein Q₁ to Q₉ may each independently be:

deuterium, —F, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, —F, a C₁-C₁₀ alkyl group, a phenyl group, or a combination thereof.

In one or more embodiments, Z₁ to Z₈ and R₁ to R₆ in Formulae 1-1, 1-2, 1-3, 2-1, 2-2, and 2-3 may each independently be: hydrogen, deuterium, —F, or a cyano group;

a C₁-C₂₀ alkyl group unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof;

a C₃-C₁₀ cycloalkyl group, a C₁-C₁₀ heterocycloalkyl group, a phenyl group, a biphenyl group, a naphthyl group, a pyridinyl group, a fluorenyl group, a carbazolyl group, a dibenzofuranyl group, or a dibenzothiophenyl group, each unsubstituted or substituted with at least one of deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof; or

—Si(Q₃)(Q₄)(Q₅) or —Ge(Q₃)(Q₄)(Q₅).

In one or more embodiments, Z₁ to Z₈ and R₁ to R₆ in Formulae 1-1, 1-2, 1-3, 2-1, 2-2, and 2-3 may each independently be hydrogen, deuterium, —F, —CH₃, —CD₃, —CD₂H, —CDH₂, —CF₃, —CF₂H, —CFH₂, a C₂-C₁₀ alkenyl group, a C₁-C₁₀ alkoxy group, a C₁-C₁₀ alkylthio group, a group represented by one of Formulae 9- 1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-227, a group represented by one of Formulae 9-201 to 9-227 in which at least one hydrogen is substituted with deuterium, a group represented by one of Formulae 9-201 to 9-227 in which at least one hydrogen is substituted with —F, a group represented by one of Formulae 10-1 to 10-129, a group represented by one of Formulae 10-1 to 10-129 in which at least one hydrogen is substituted with deuterium, a group represented by one of Formulae 10-1 to 10-129 in which at least one hydrogen is substituted with —F, a group represented by one of Formulae 10-201 to 10-350, a group represented by one of Formulae 10-201 to 10-350 in which at least one hydrogen is substituted with deuterium, a group represented by one of Formulae 10-201 to 10-350 in which at least one hydrogen is substituted with —F, —Si(Q₃)(Q₄)(Q₅), or —Ge(Q₃)(Q₄)(Q₅) (wherein 03 to 05 are as described herein):

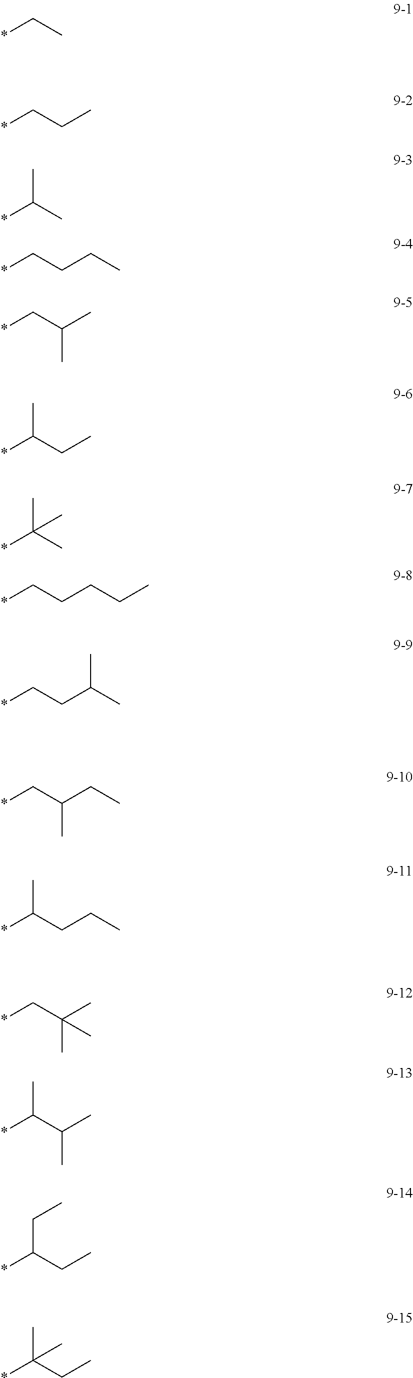

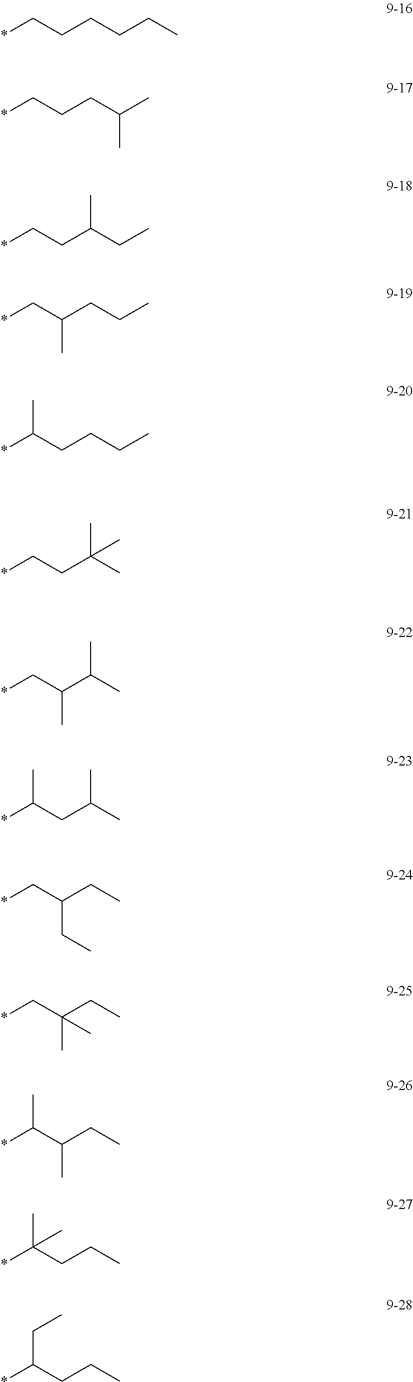

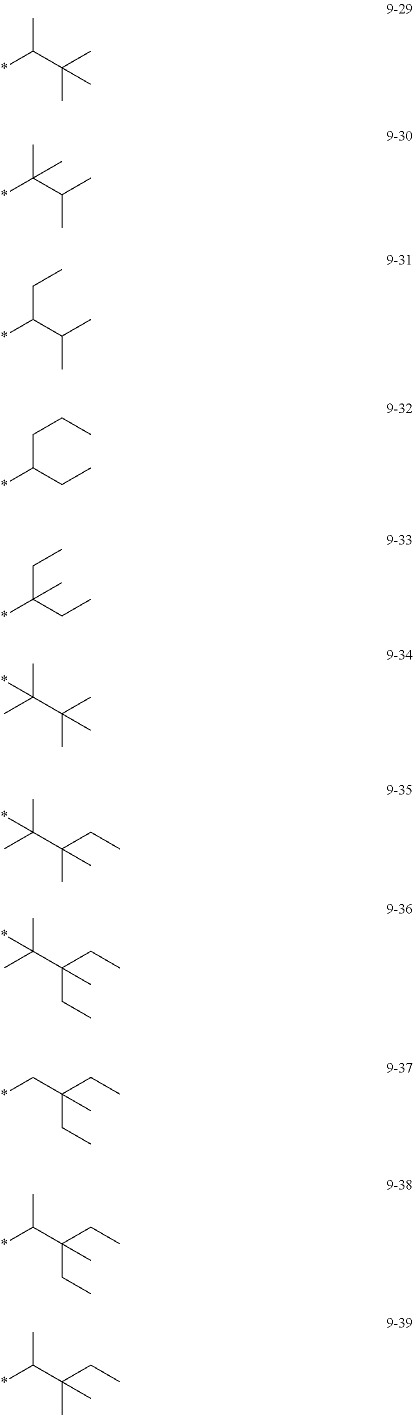

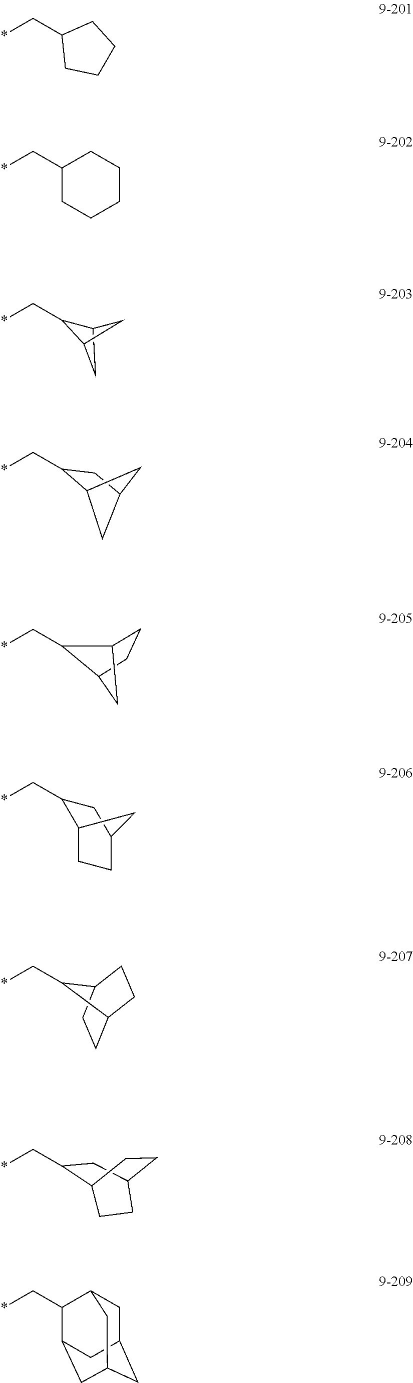

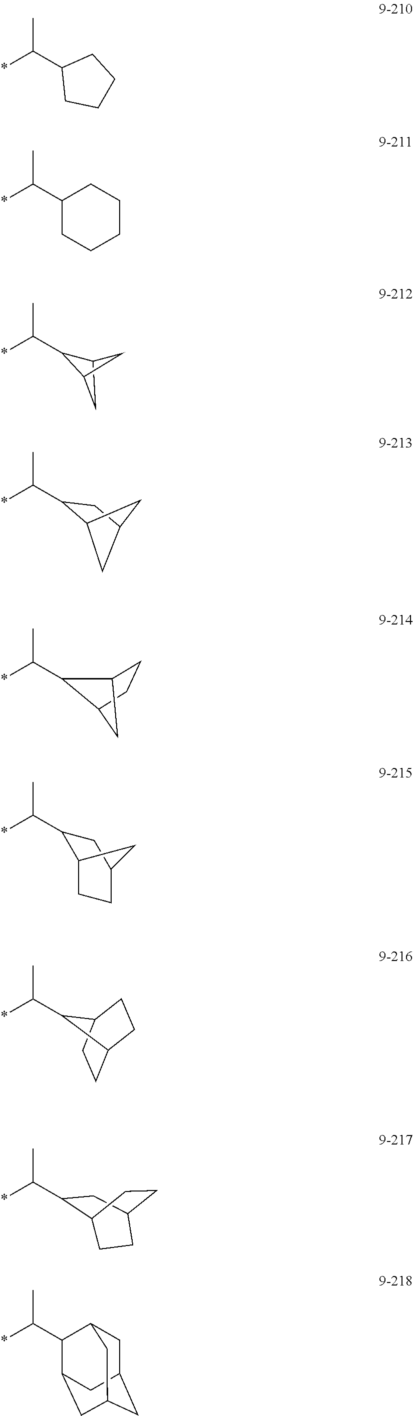

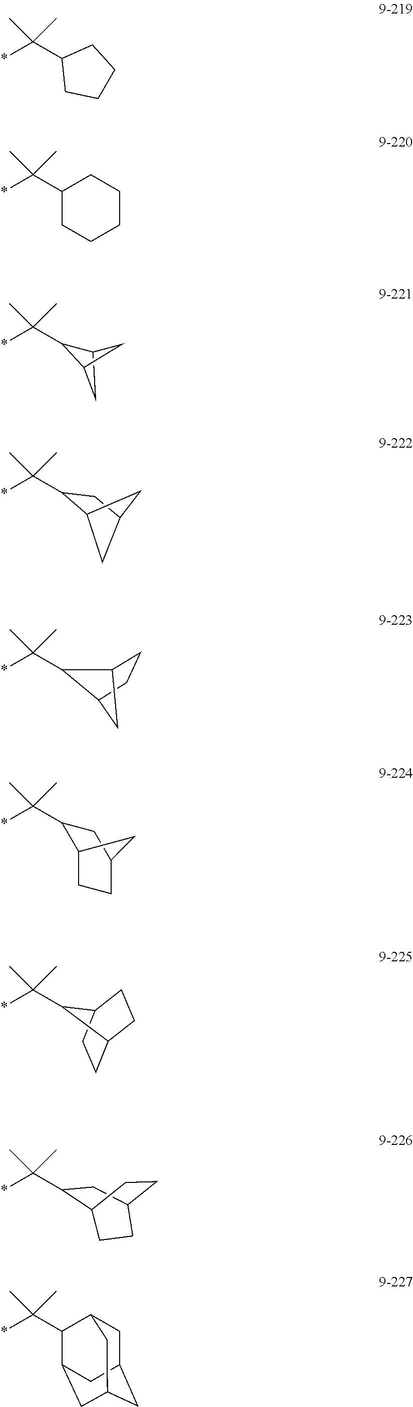

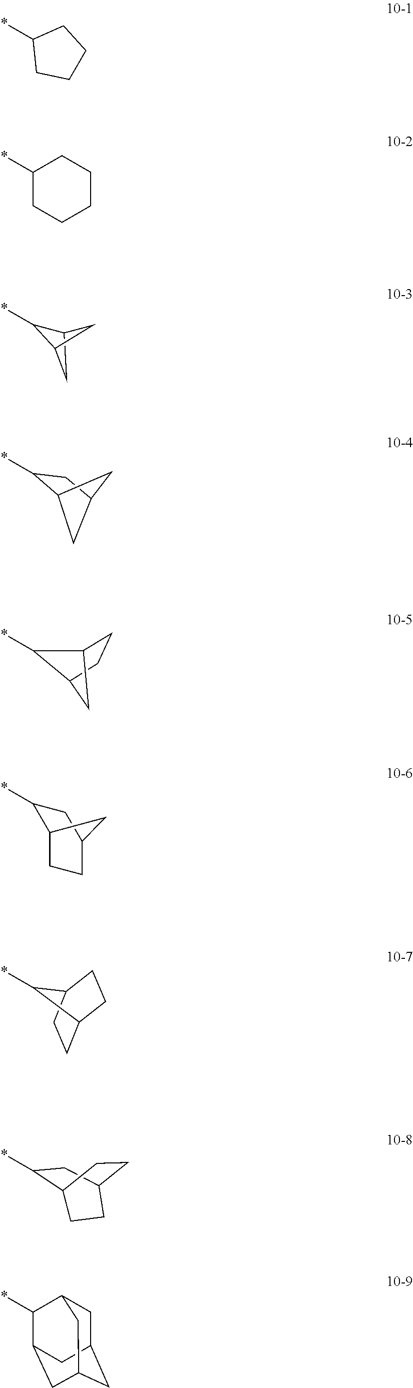

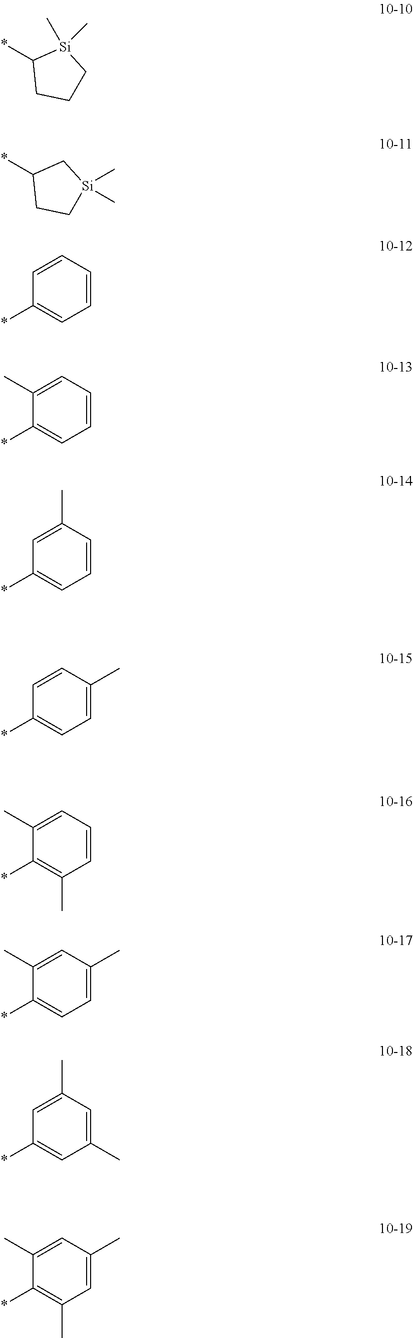

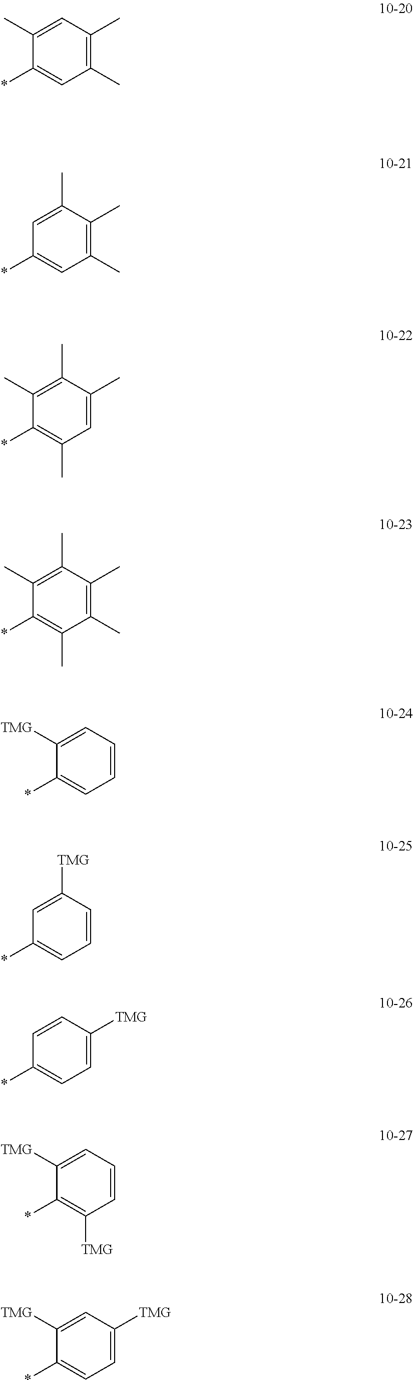

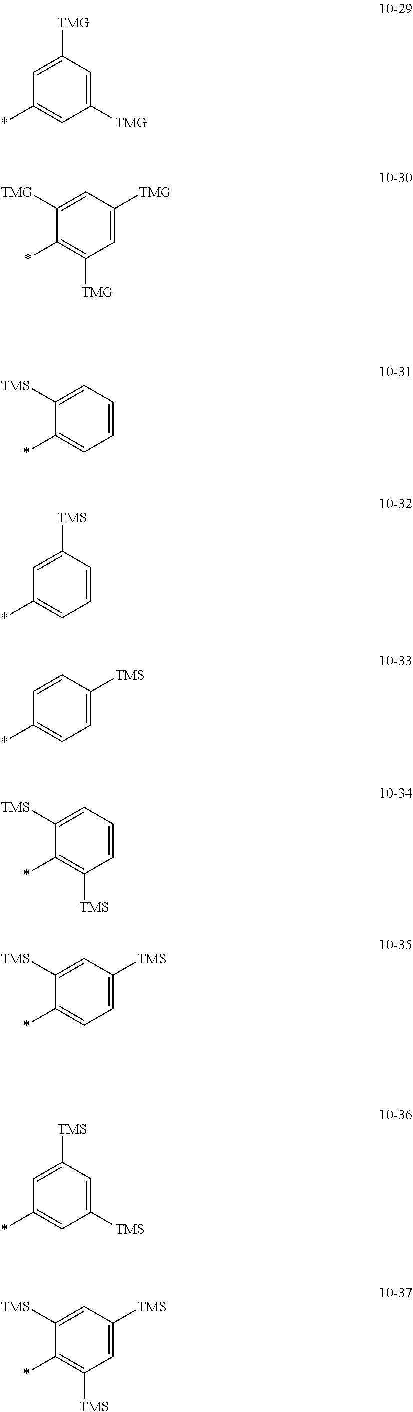

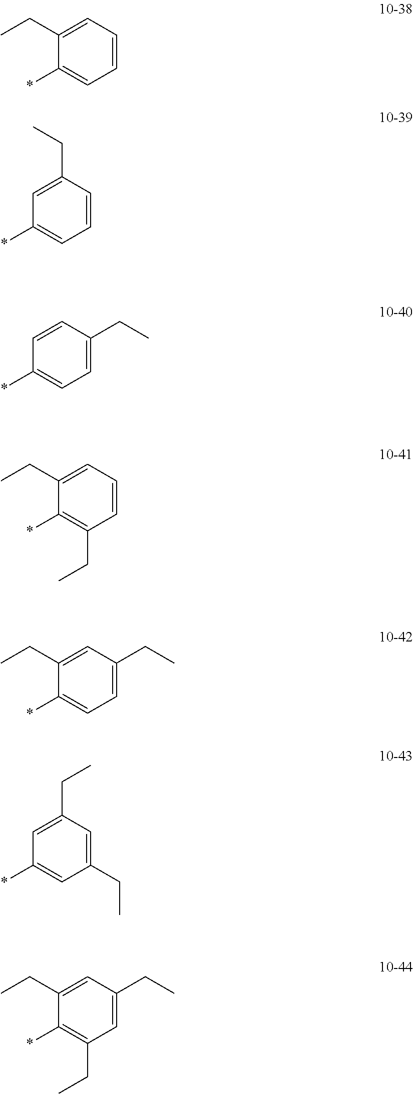

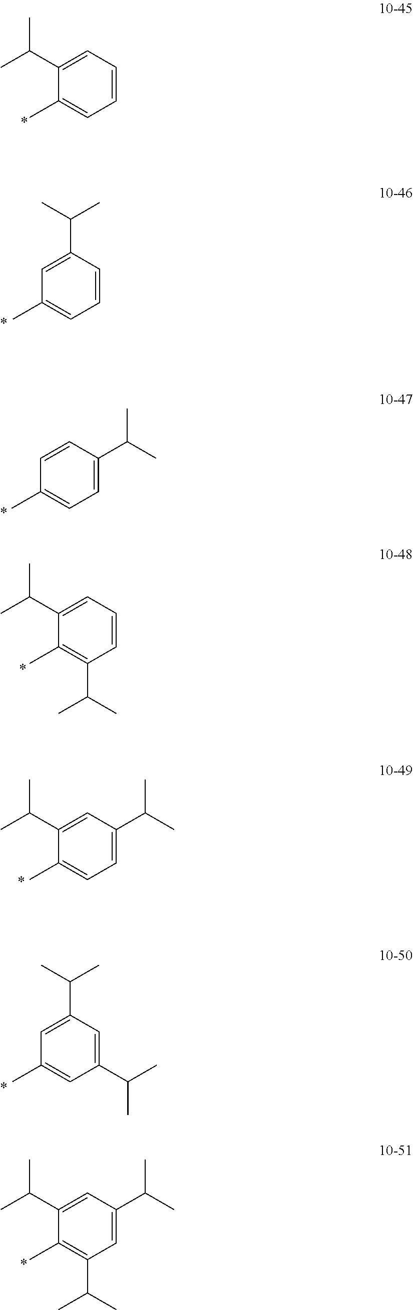

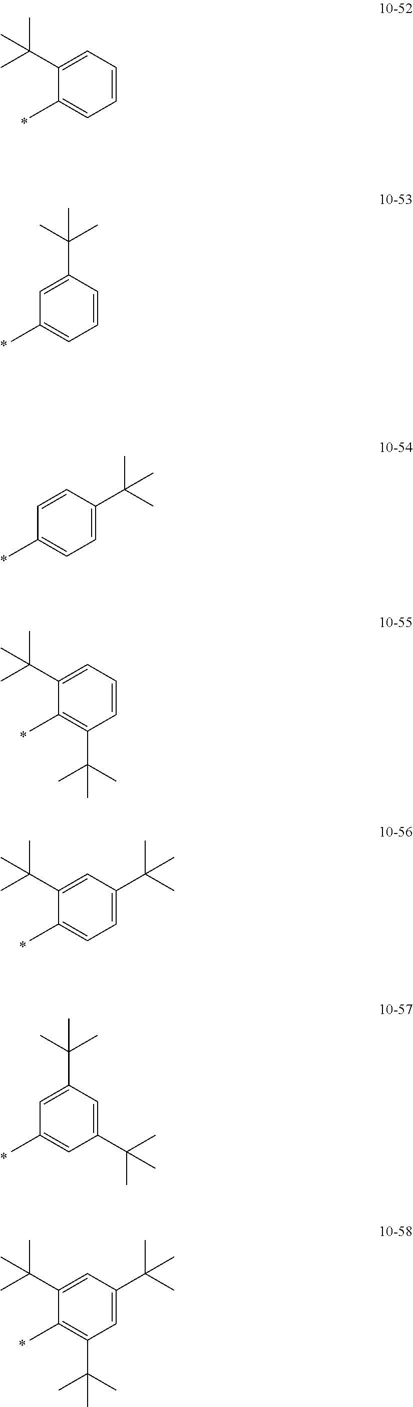

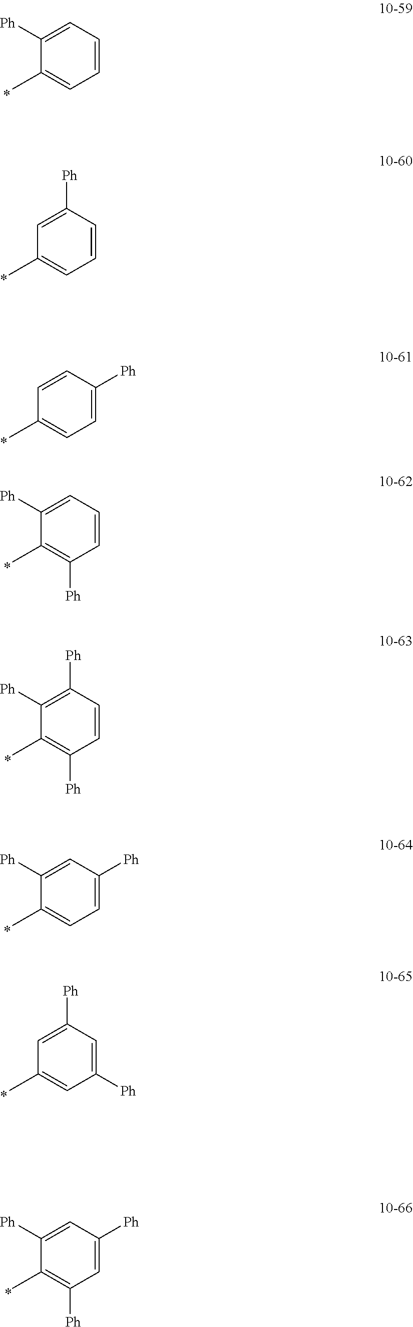

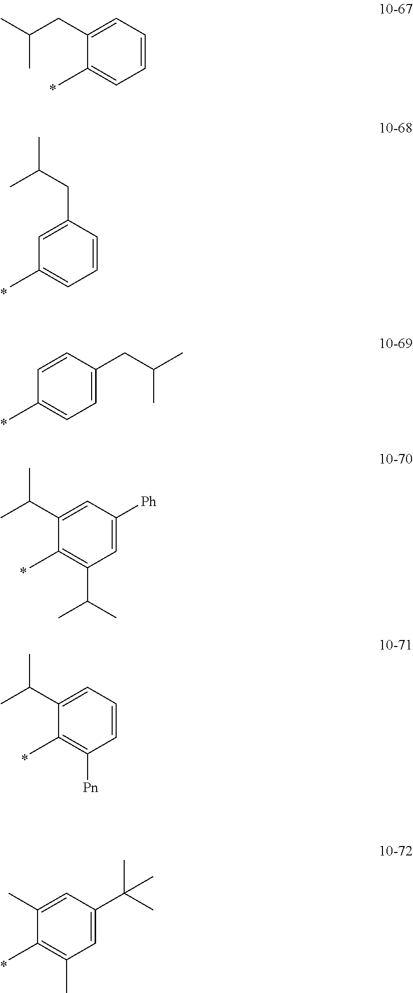

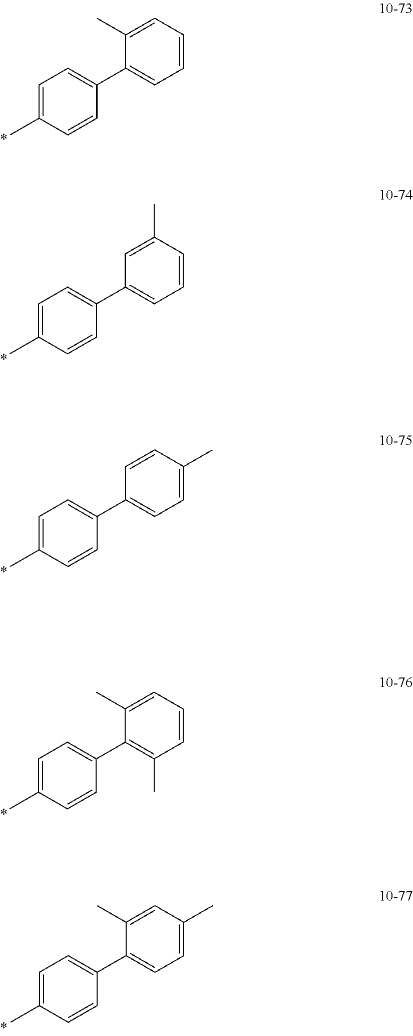

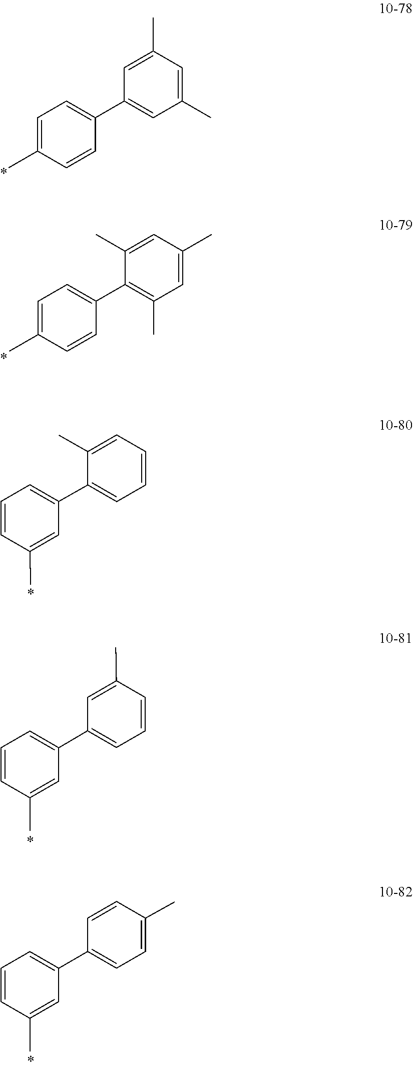

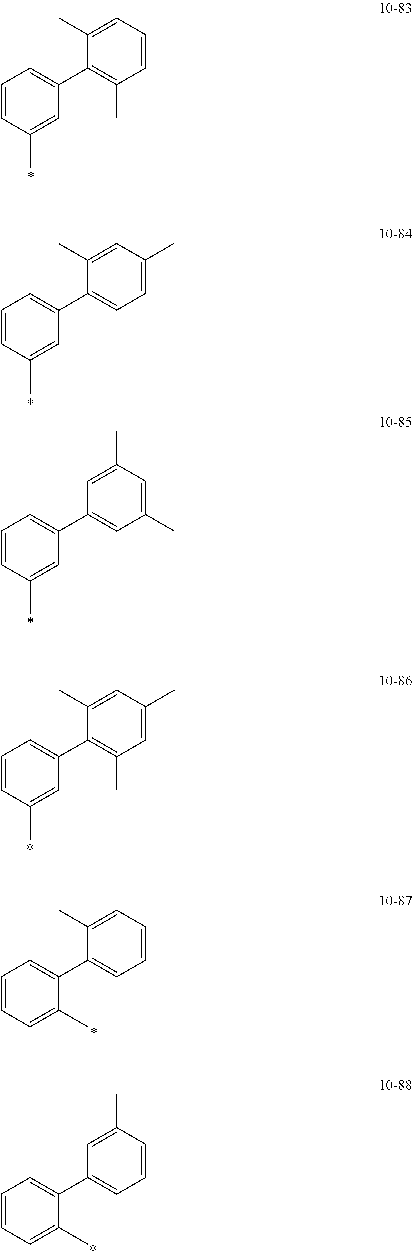

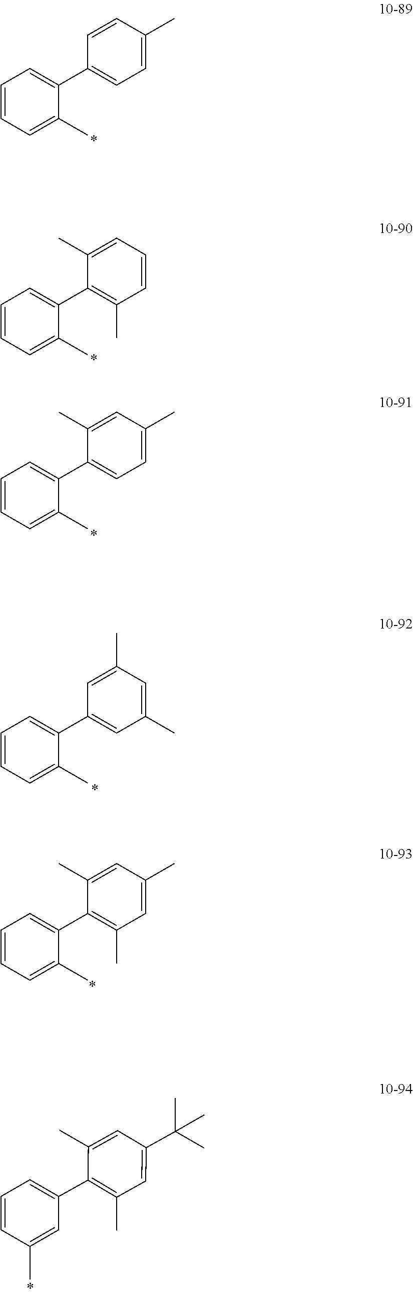

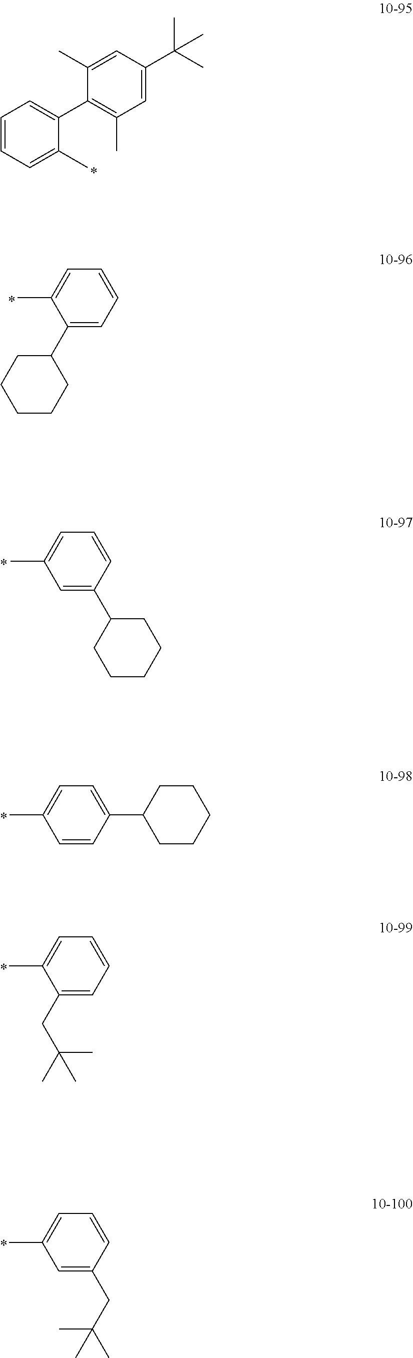

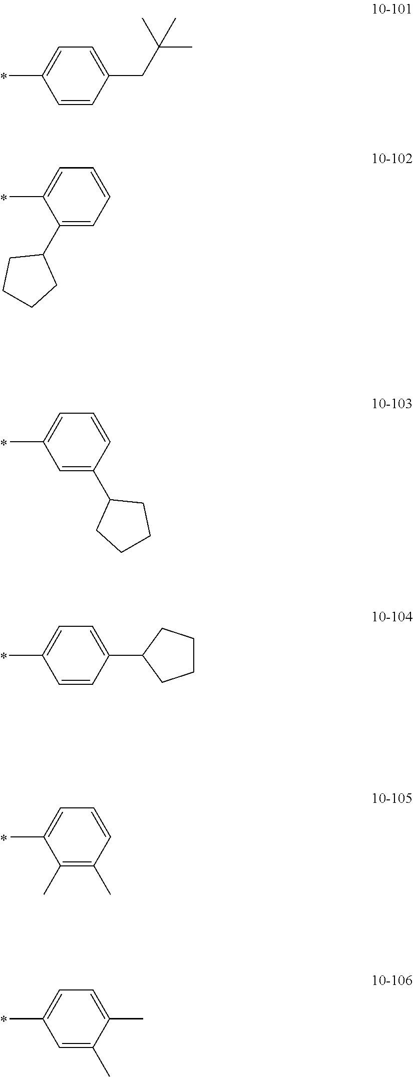

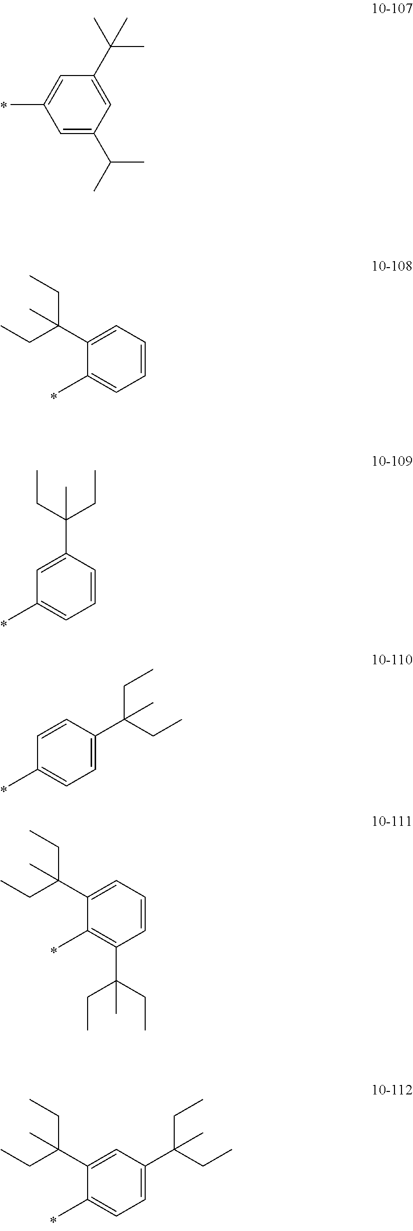

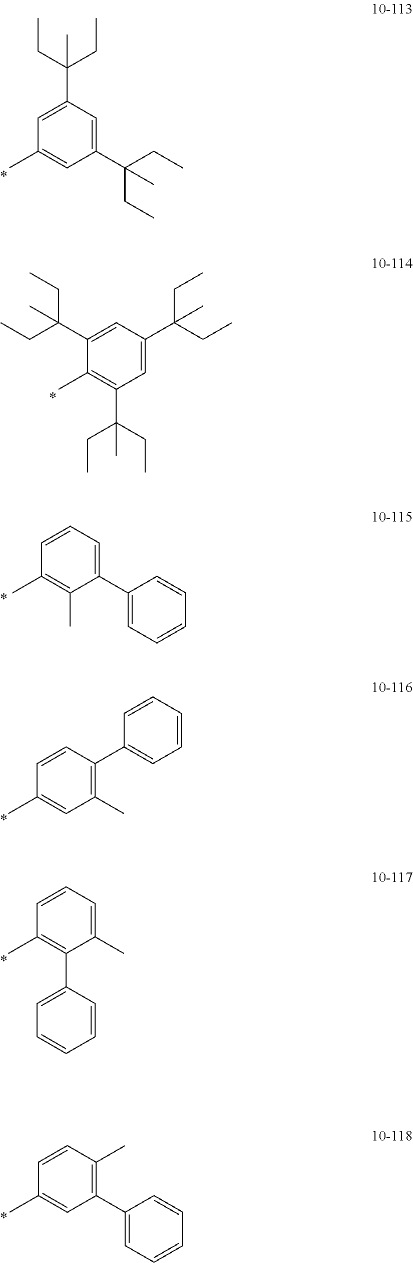

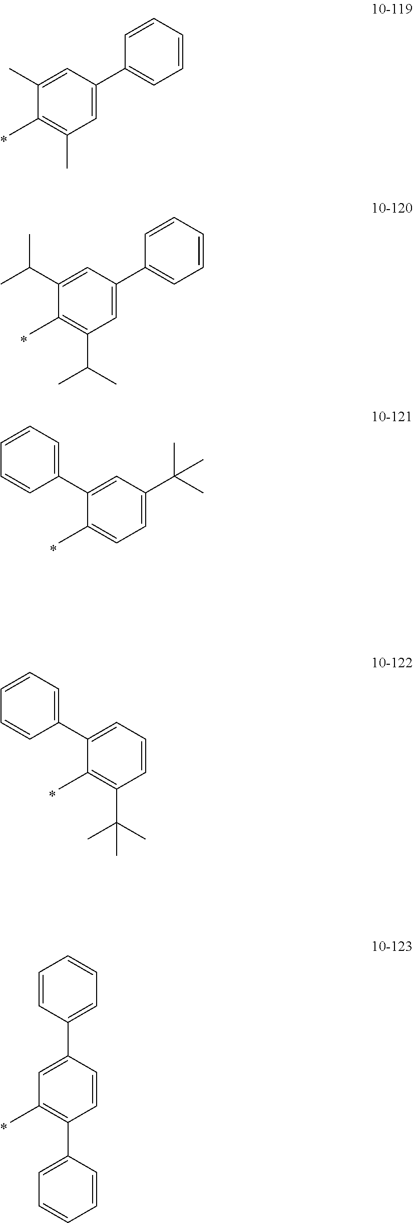

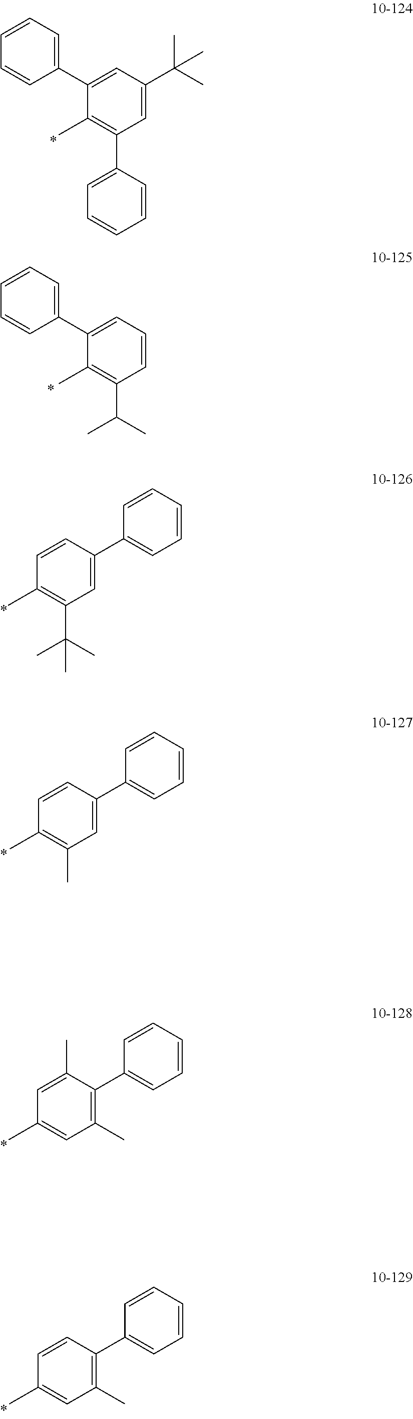

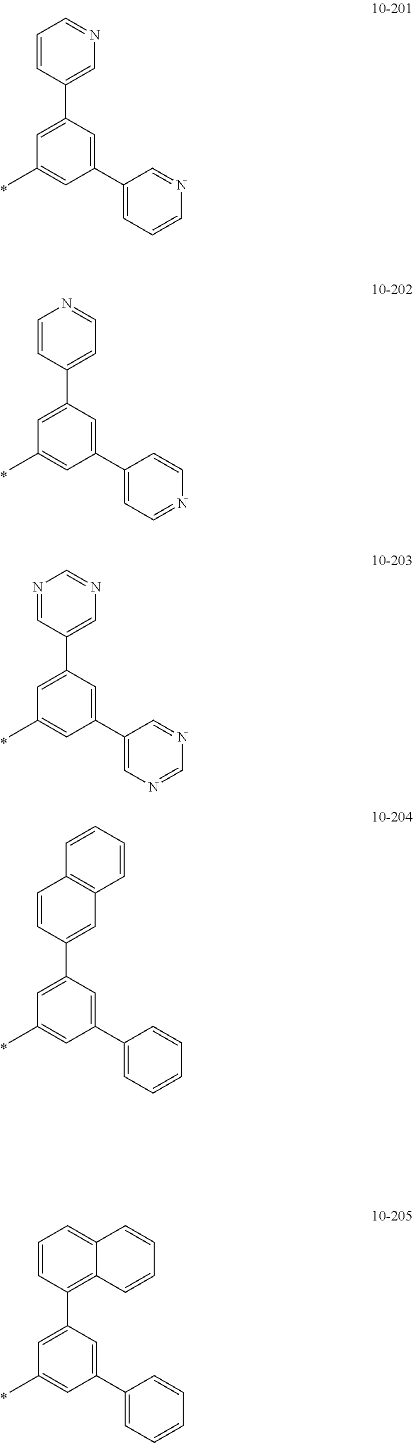

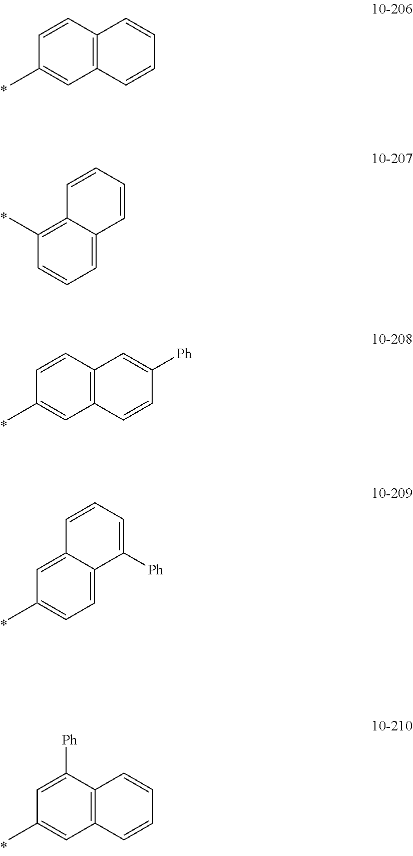

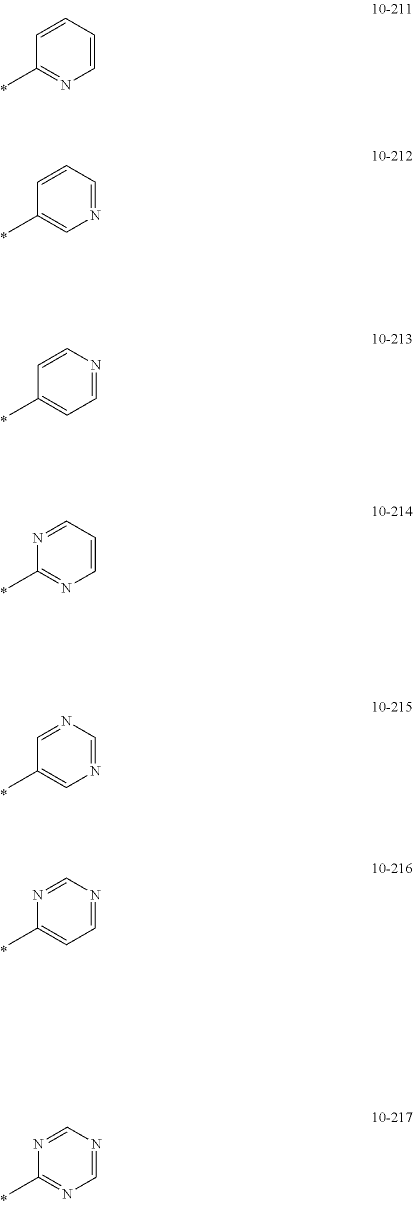

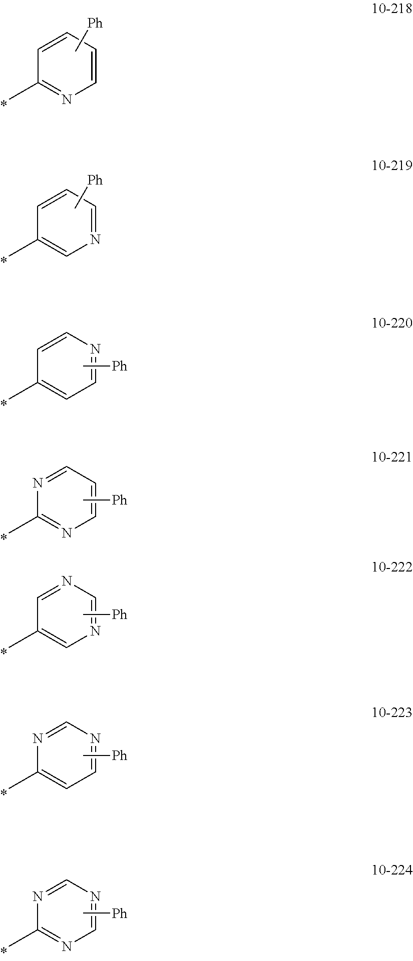

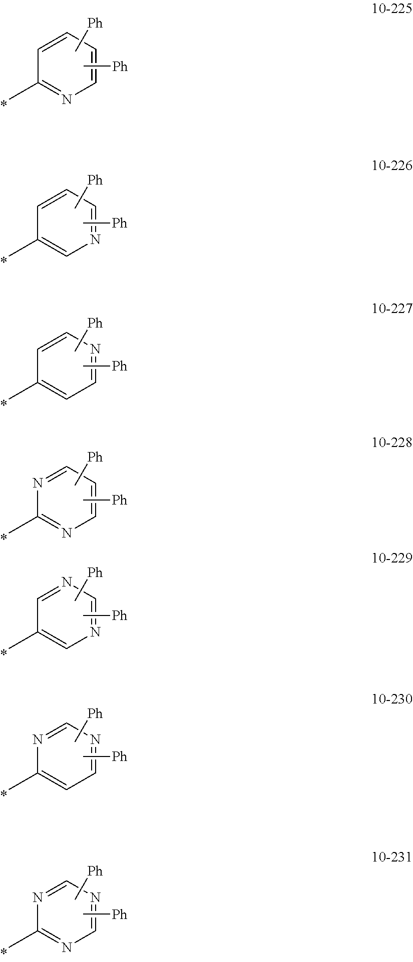

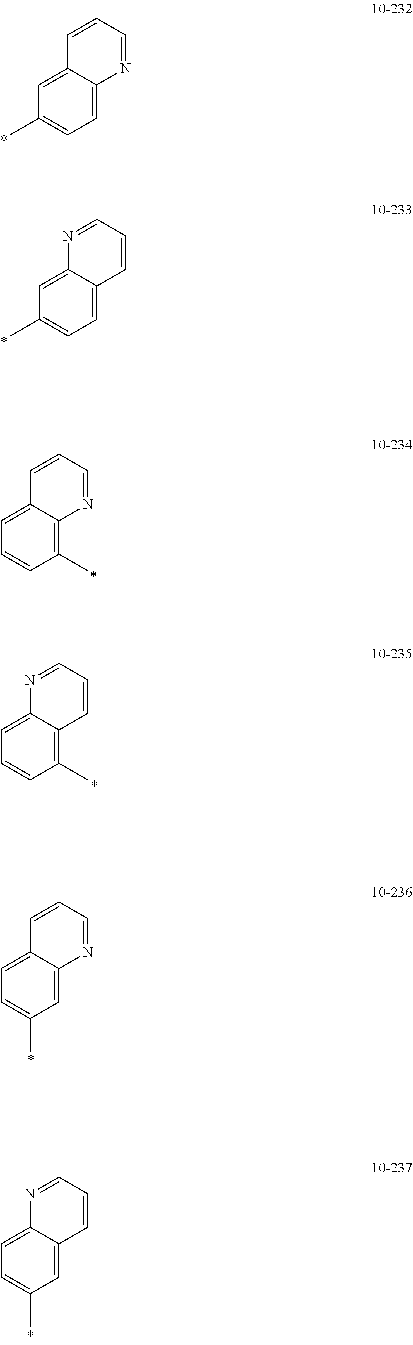

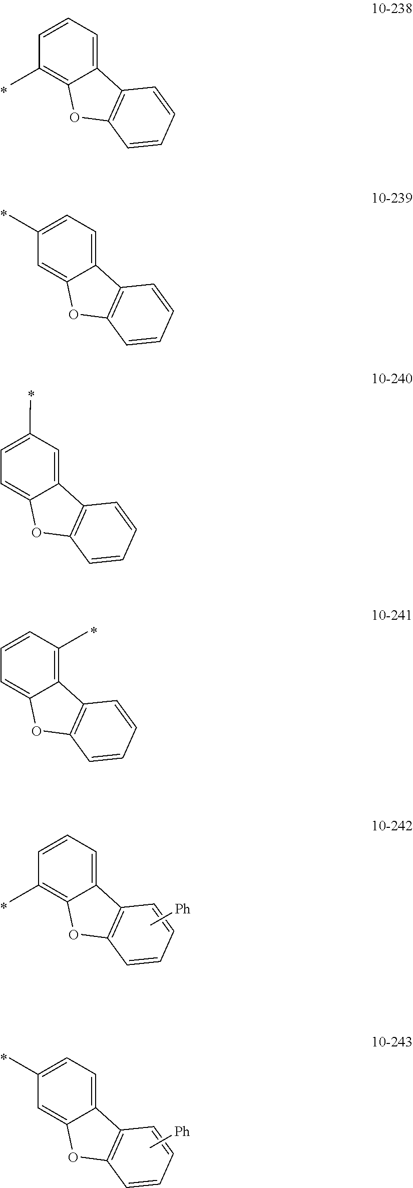

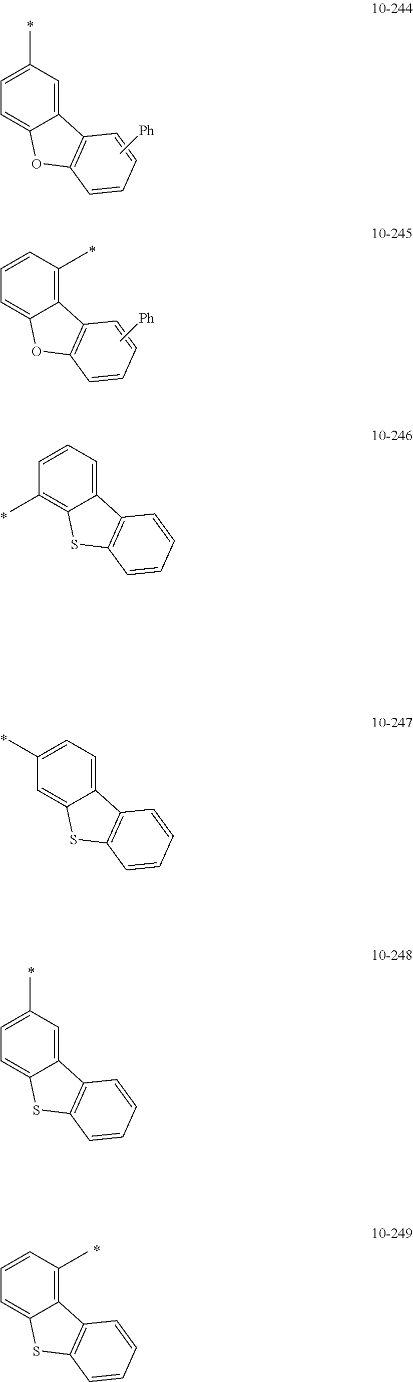

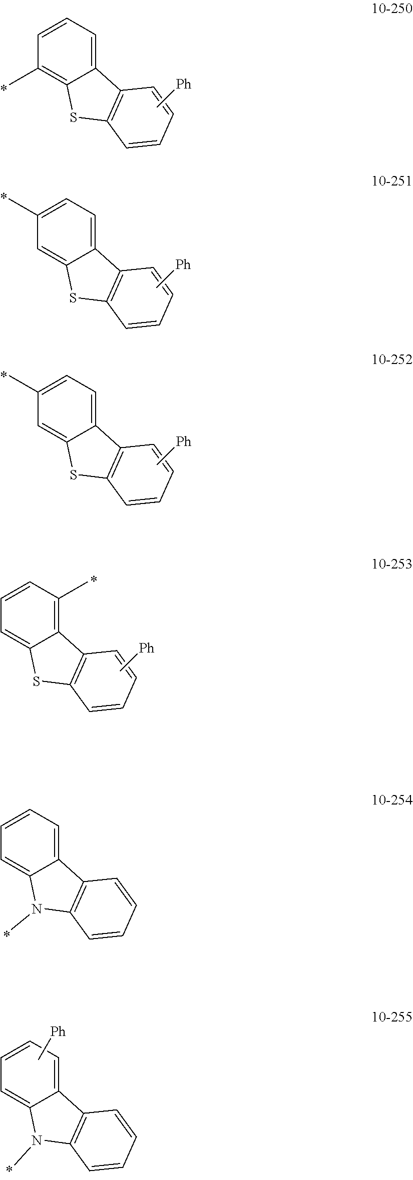

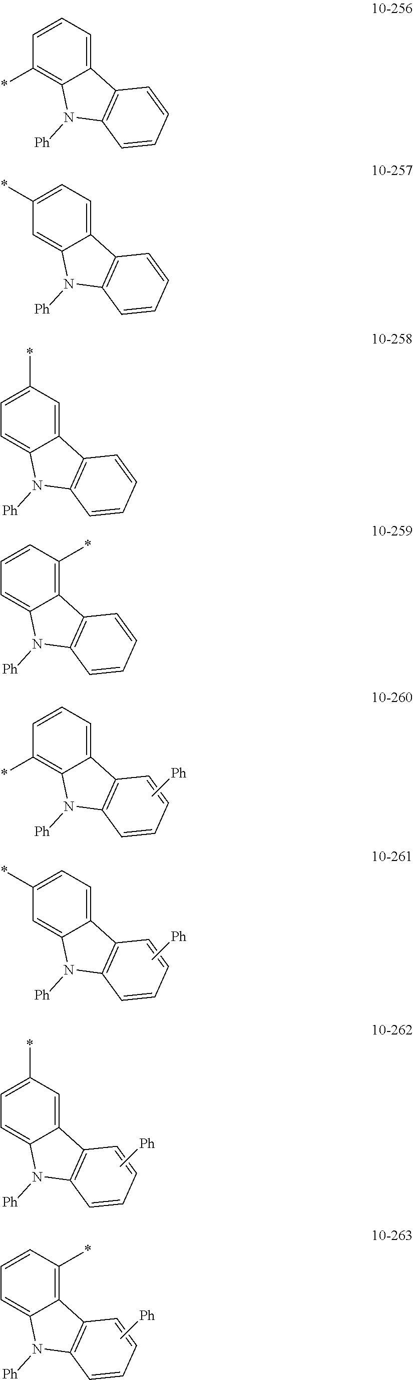

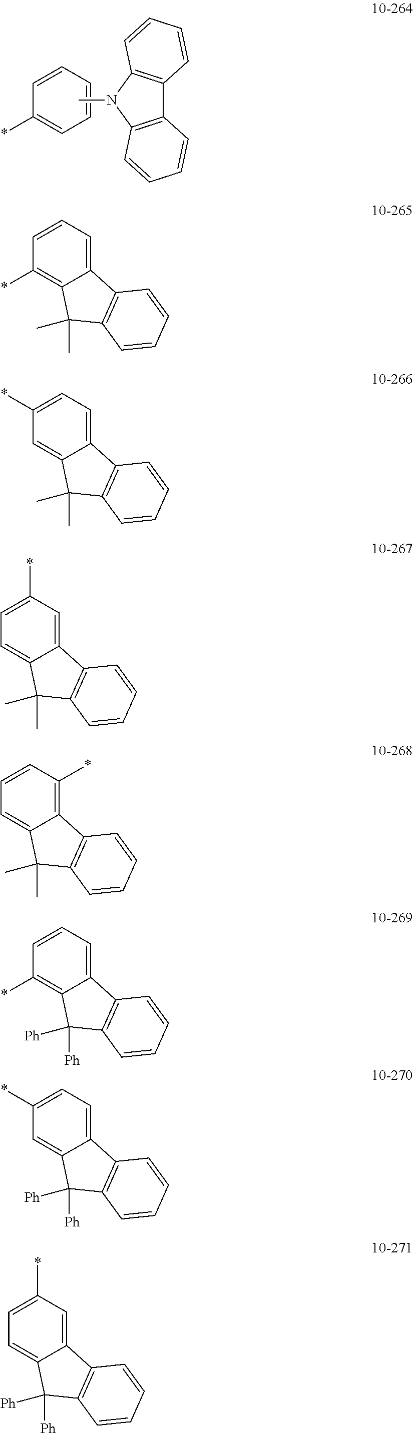

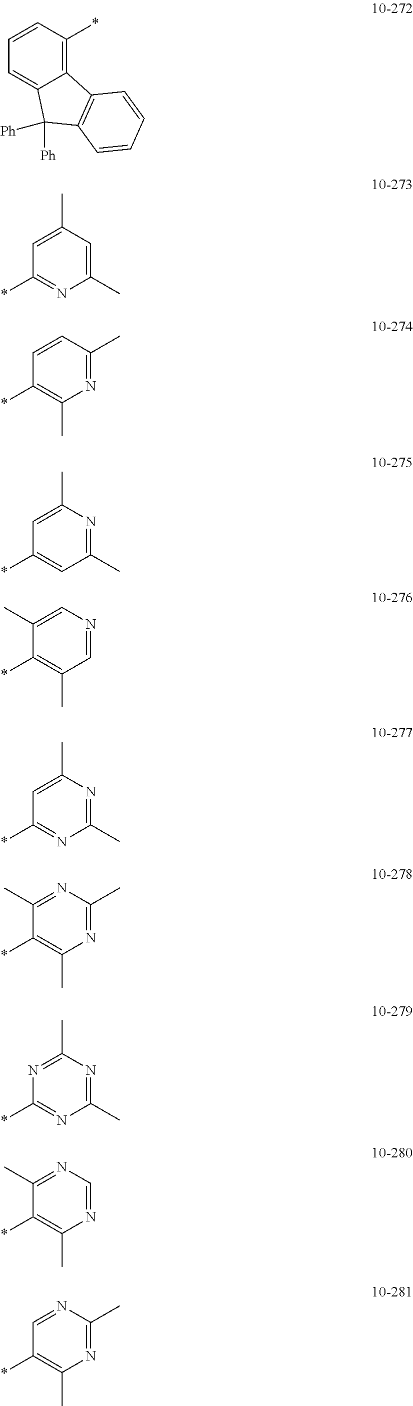

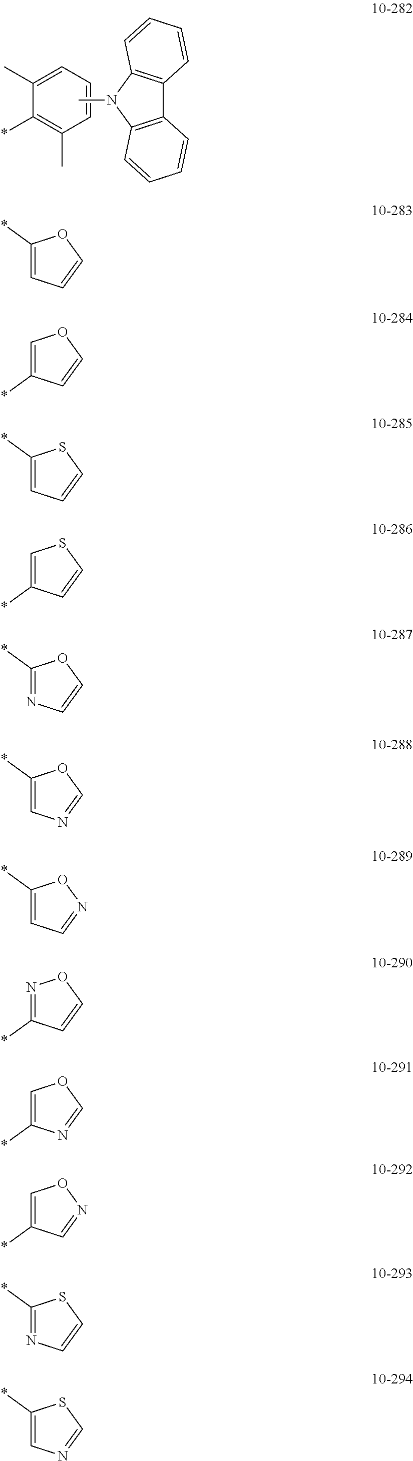

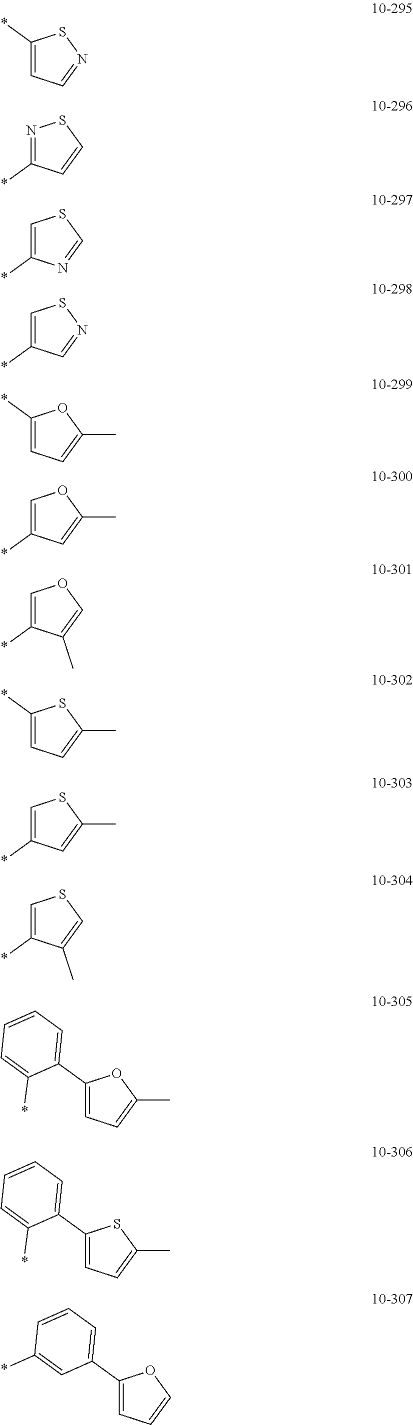

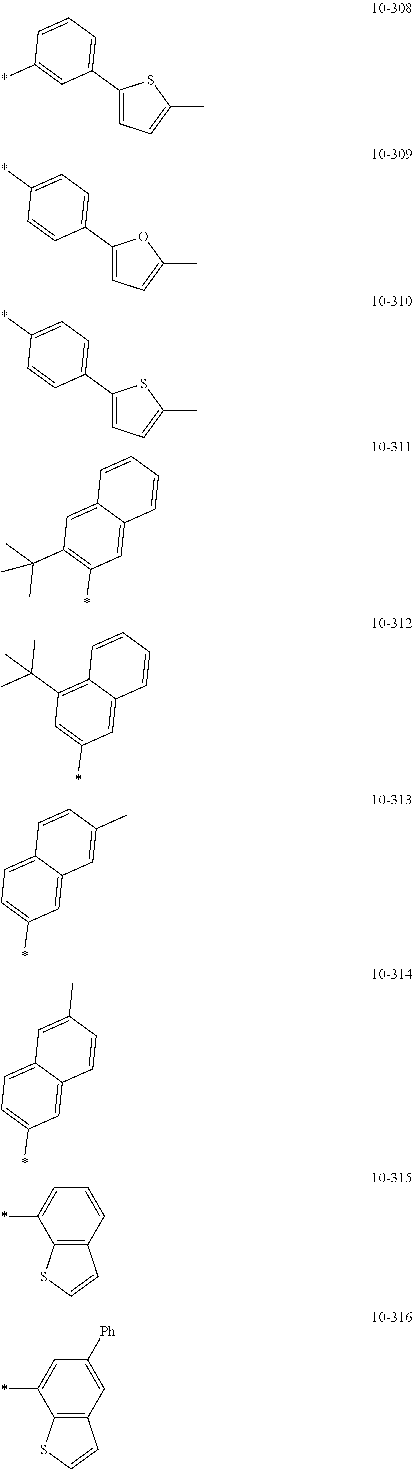

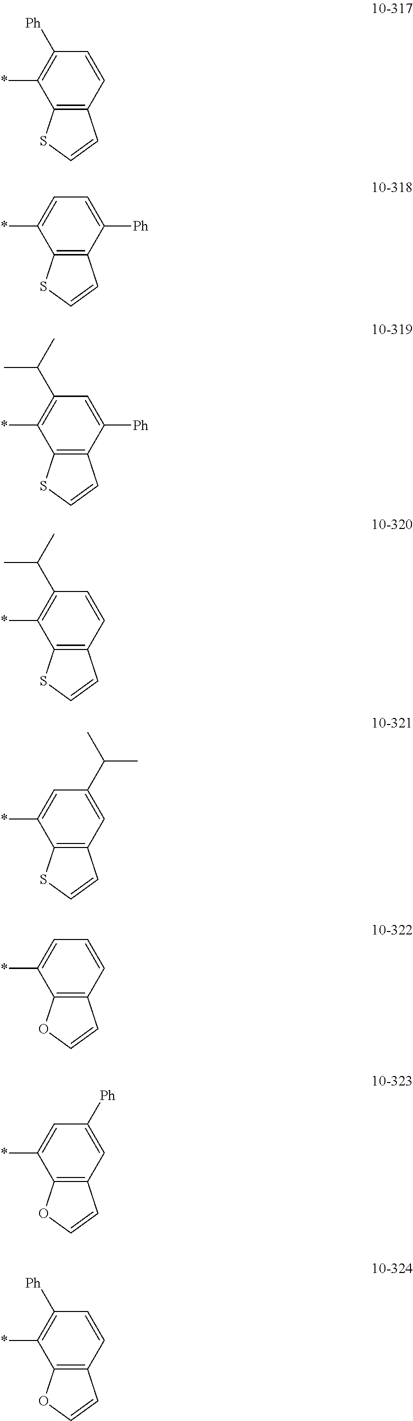

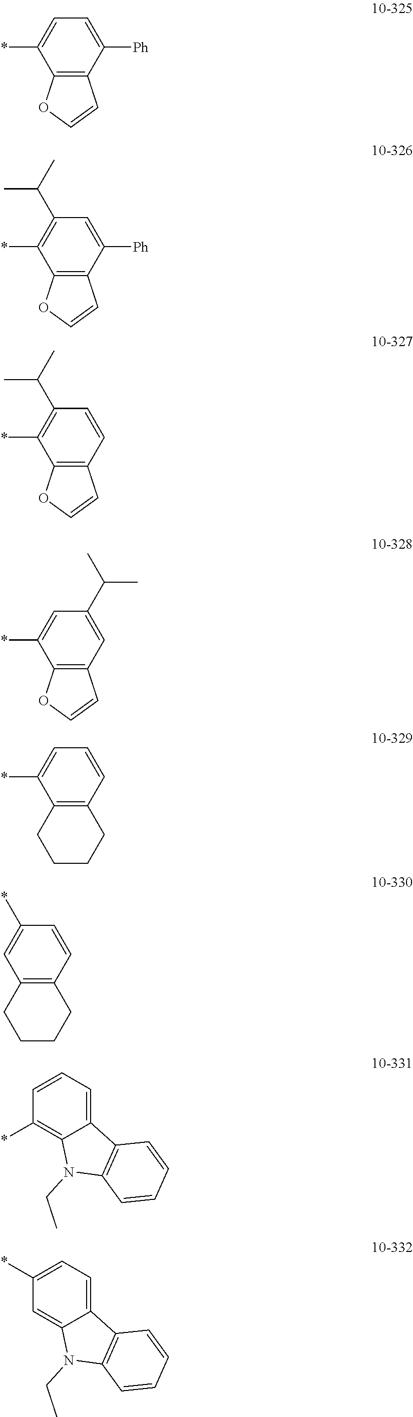

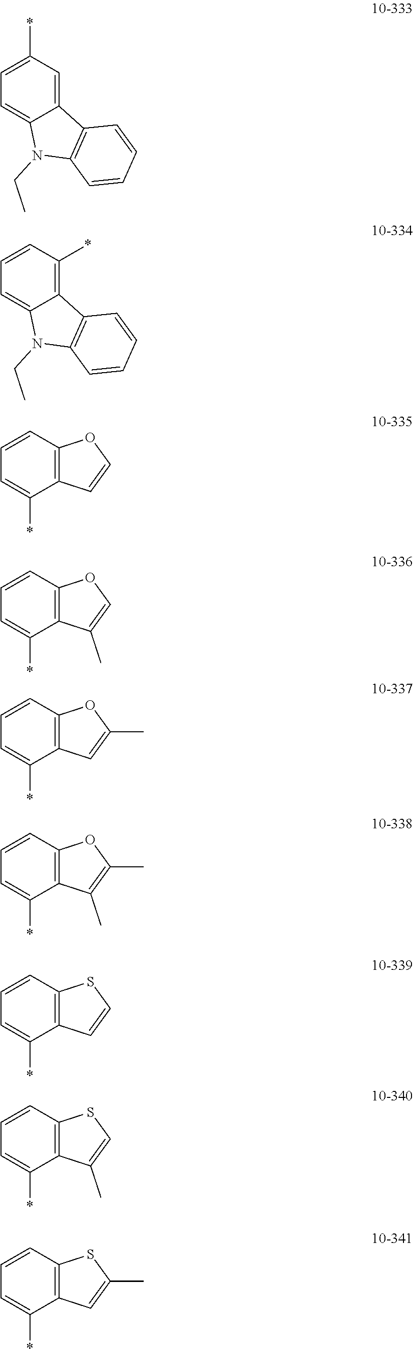

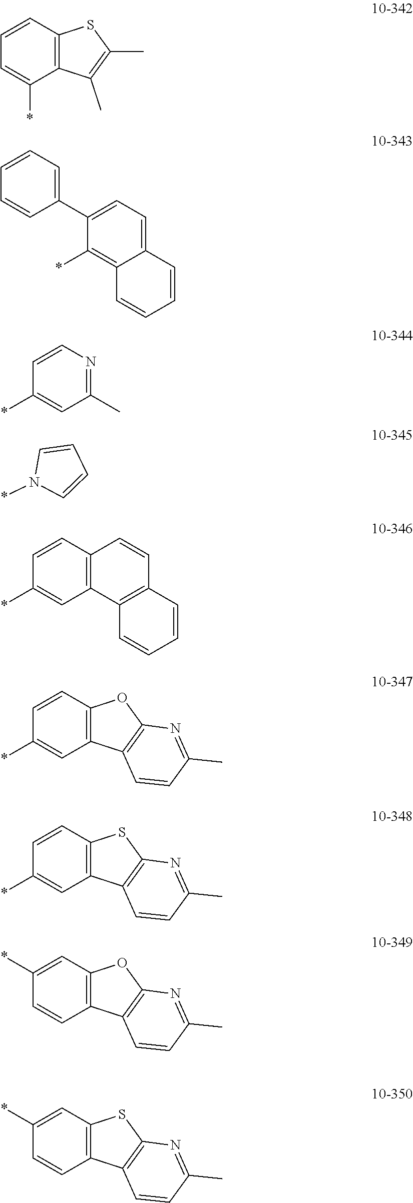

wherein, in Formulae 9-1 to 9-39, 9-201 to 9-227, 10-1 to 10-129, and 10-201 to 10-350,
* indicates a binding site to a neighboring atom, Ph indicates a phenyl group, TMS indicates a trimethylsilyl group, and TMG indicates a trimethylgermyl group.

The “group represented by one of Formulae 9-1 to 9-39 in which at least one hydrogen is substituted with deuterium” and the “group represented by one of Formulae 9-201 to 9-227 in which at least one hydrogen is substituted with deuterium” may be, for example, a group represented by one of Formulae 9-501 to 9-514 and 9-601 to 9-636:

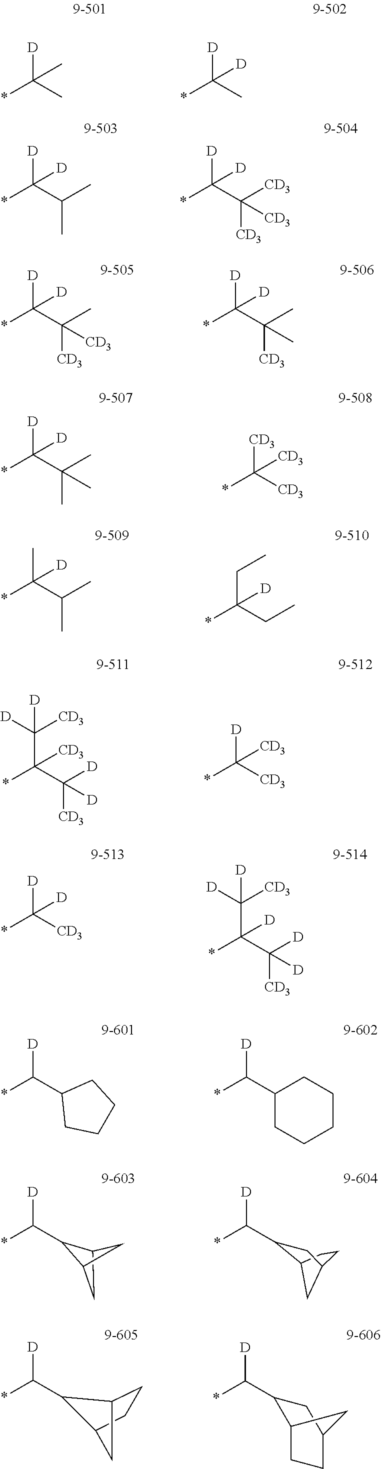

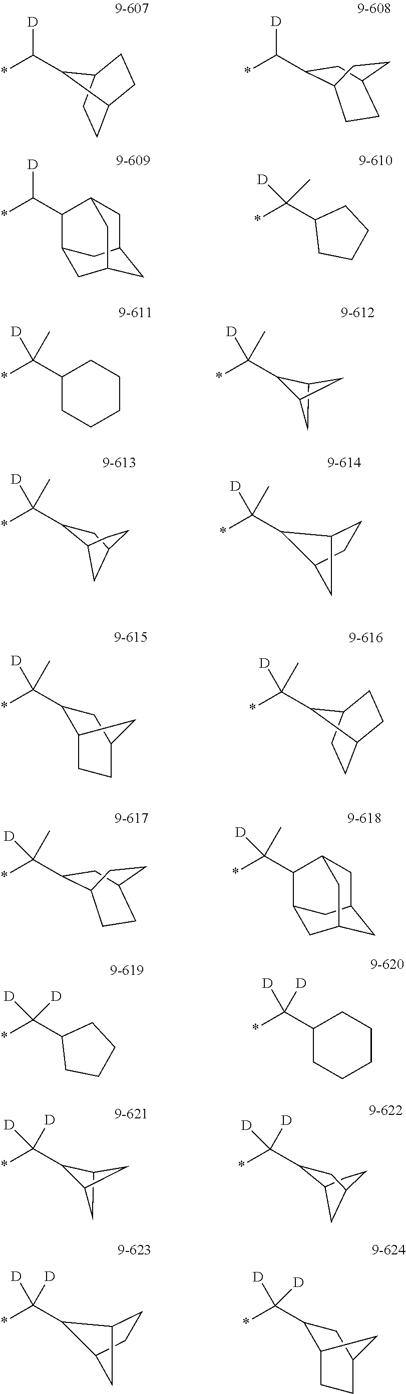

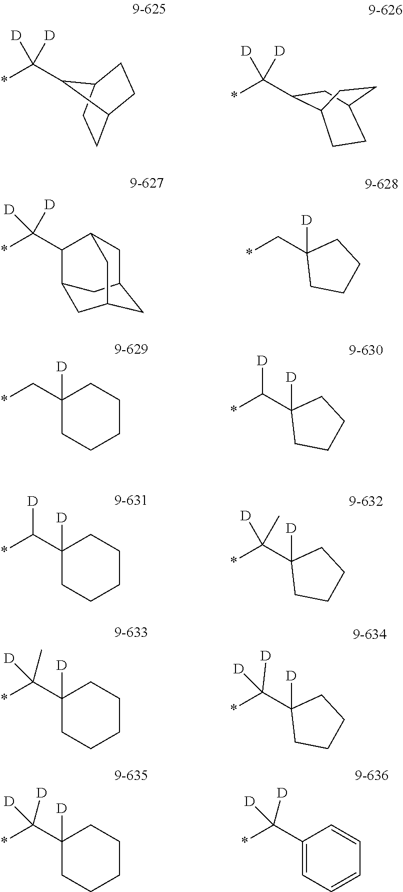

wherein * represents a binding site to a neighboring atom.
The “group represented by one of Formulae 9-1 to 9-39 in which at least one hydrogen is substituted with —F” and the “group represented by one of Formulae 9-201 to 9-227 in which at least one hydrogen is substituted with —F” may be, for example, a group represented by one of Formulae 9-701 to 9-710:

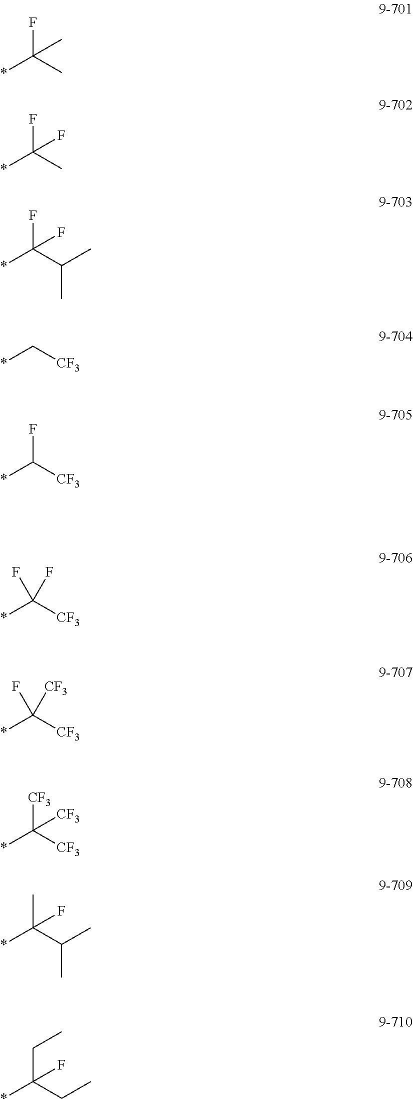

wherein * represents a binding site to a neighboring atom.

The “group represented by one of Formulae 10-1 to 10-129 in which at least one hydrogen is substituted with deuterium” and the “group represented by one of Formulae 10-201 to 10-350 in which at least one hydrogen is substituted with deuterium” may be, for example, a group represented by one of Formulae 10-501 to 10-553:

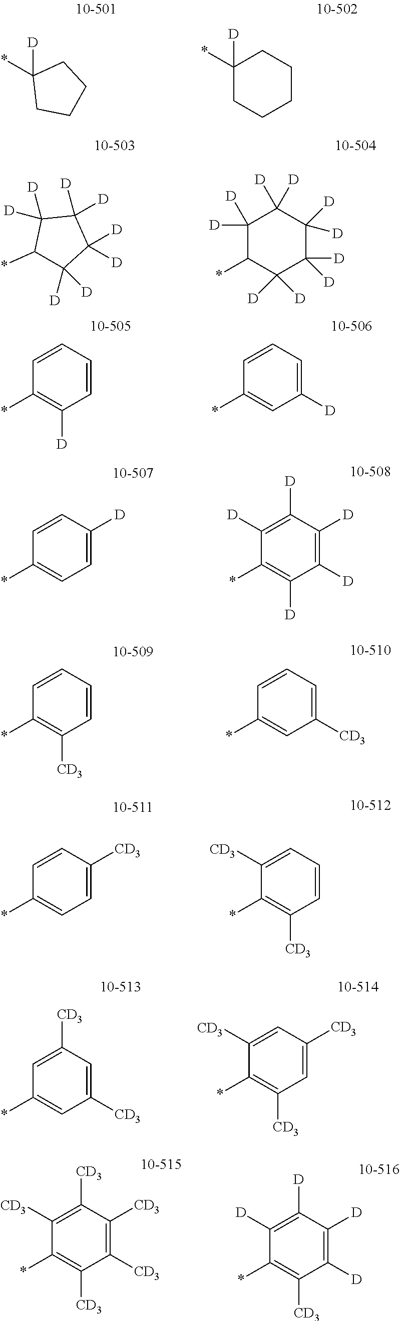

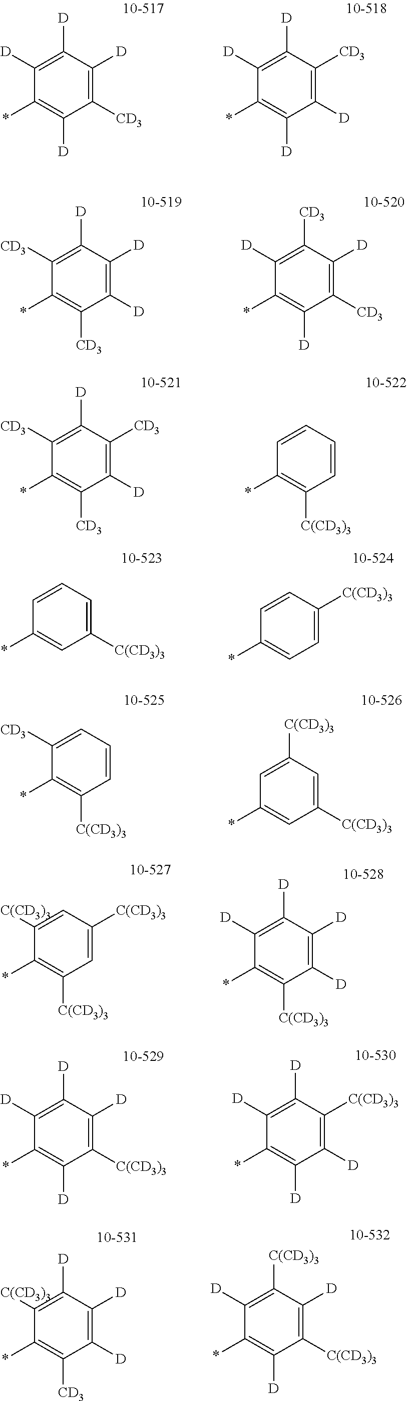

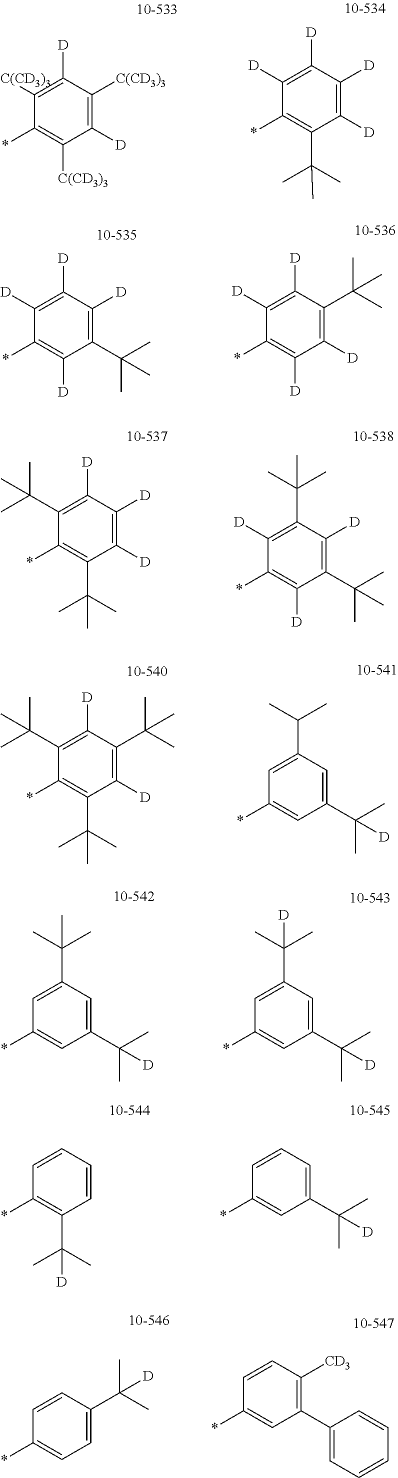

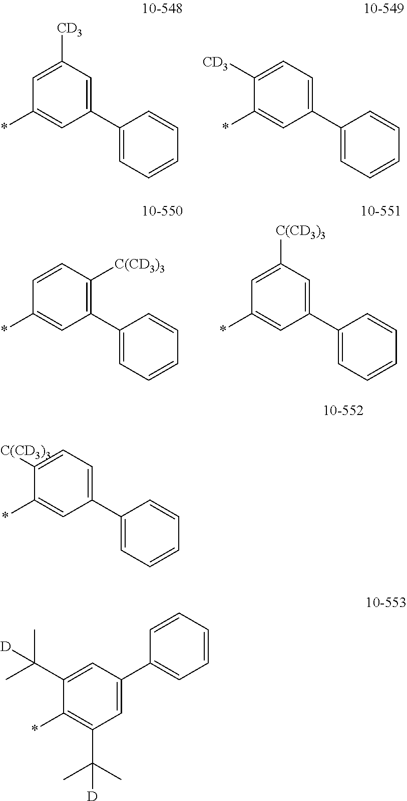

wherein * represents a binding site to a neighboring atom.

The “group represented by one of Formulae 10-1 to 10-129 in which at least one hydrogen is substituted with —F” and the “group represented by Formulae 10-201 to 10-350 in which at least one hydrogen is substituted with —F” may be, for example, a group represented by one of Formulae 10-601 to 10-617:

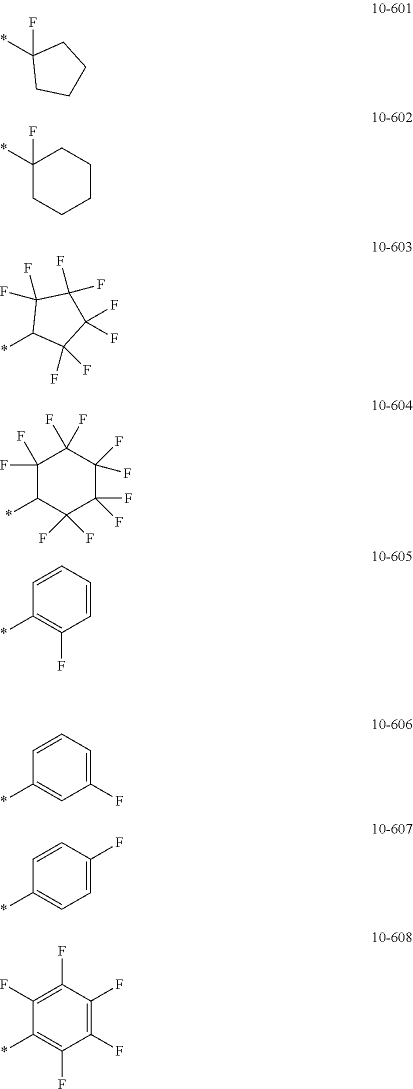

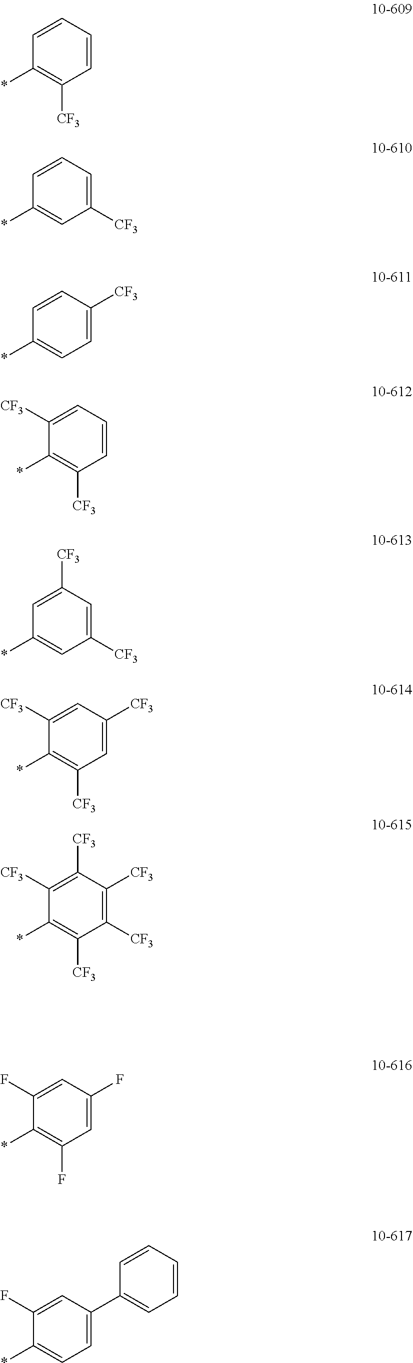

wherein * represents a binding site to a neighboring atom.

At least one of R₁ and R₂ in Formula 1-3 (for example, R₁ and R₂) may each independently have 4 or more, 5 or more, or 6 or more carbon atoms.

In an embodiment, R₁ in Formula 1-3 may not be a methyl group.

In one or more embodiments, R₁ and R₂ in Formula 1-3 may each not be a methyl group.

In one or more embodiments, R₁ in Formula 1-3 may not be a tert-butyl group.

In one or more embodiments, R₁ and R₂ in Formula 1-3 may each not be a tert-butyl group.

In one or more embodiments, Formula 1-3 may satisfy at least one of Conditions E1 to E3, or each of Conditions E1 and E2:

Condition E1
R₁ is a group represented by *—C(R₁₁)(R₁₂)(R₁₃), and
R₁₁ to R₁₃ are each independently a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition E2
R₁ is a group represented by *—C(R₁₁)(R₁₂)(R₁₃), and
at least one of R₁₁ to R₁₃ are each independently a substituted or unsubstituted C₂-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition E3
R₁ is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group.

In one or more embodiments, Formula 1-3 may satisfy at least one of Conditions F1 to F3, or each of Conditions F1 and F2:

Condition F1

R₂ is a group represented by *—C(R₂₁)(R₂₂)(R₂₃), and

R₂₁ to R₂₃ are each independently a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group

Condition F2
R₂ is a group represented by *—C(R₂₁)(R₂₂)(R₂₃), and
at least one of R₂₁ to R₂₃ are each independently a substituted or unsubstituted C₂-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition F3
R₂ is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group.

In one or more embodiments, R₃ in Formula 1-3 may be hydrogen or deuterium.

In one or more embodiments, R₁ and R₂ in Formula 1-3 may be identical to each other.

In one or more embodiments, R₁ and R₂ in Formula 1-3 may be different from each other.

In one or more embodiments, at least one of R₄ and R₅ in Formula 2-3 may be a methyl group.

In one or more embodiments, at least one of R₄ and R₅ in Formula 2-3 may be a tert-butyl group.

In one or more embodiments, Formula 2-3 may satisfy i) at least one of Conditions G1 to G3, or ii) both Conditions G1 and G2:

Condition G1
R₄ is a group represented by *—C(R₄₁)(R₄₂)(R₄₃), and
R₄₁ to R₄₃ are each independently a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition G2
R₄ is a group represented by *—C(R₄₁)(R₄₂)(R₄₃), and
at least one of R₄₁ to R₄₃ are each independently a substituted or unsubstituted C₂-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition G3
R₄ is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group.

In one or more embodiments, Formula 2-3 may satisfy at least one of Conditions H1 to H3, or each of Conditions H1 and H2:

Condition H1
R₅ is a group represented by *—C(R₅₁)(R₅₂)(R₅₃), and
R₅₁ to R₅₃ are each independently a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition H2
R₅ is a group represented by *—C(R₅₁)(R₅₂)(R₅₃), and
at least one of R₅₁ to R₅₃ are each independently a substituted or unsubstituted C₂-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group;

Condition H3
R₅ is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group.

In one or more embodiments, R₆ in Formula 2-3 may be hydrogen or deuterium.

In one or more embodiments, R₄ and R₅ in Formula 2-3 may be identical to each other.

In one or more embodiments, R₄ and R₅ in Formula 2-3 may be different from each other.

e1 to e8 and d1 to d8 in Formulae 1-1, 1-2, 2-1, and 2-2 indicate the numbers of Z₁ to Z₈, a group represented by *—[W₁—(Z₁)ₑ₁], a group represented by *—[W₂—(Z₂)ₑ₂], a group represented by *—[W₃—(Z₃)ₑ₃], a group represented by *—[W₄—(Z₄)ₑ₄], a group represented by *—[W₅—(Z₅)ₑ₅], a group represented by *—[W₆—(Z₆)ₑ₆], a group represented by *—[W₇—(Z₇)ₑ₇], and a group represented by *—[W₈—(Z₈)ₑ₈], respectively, and may each independently be an integer from 0 to 20. When e1 is 2 or more, two or more of Z₁(s) may be identical to or different from each other, when e2 is 2 or more, two or more of Z₂(s) may be identical to or different from each other, when e3 is 2 or more, two or more of Z₃(s) may be identical to or different from each other, when e4 is 2 or more, two or more of Z₄(s) may be identical to or different from each other, when e5 is 2 or more, two or more of Z₅(s) may be identical to or different from each other, when e6 is 2 or more, two or more of Z₆(s) may be identical to or different from each other, when e7 is 2 or more, two or more of Z₇(s) may be identical to or different from each other, when e8 is 2 or more, two or more of Z₈(s) may be identical to or different from each other, when d1 is 2 or more, two or more of groups represented by *—[W₁—(Z₁)ₑ₁] may be identical to or different from each other, when d2 is 2 or more, two or more of groups represented by *—[W₂—(Z₂)ₑ₂] may be identical to or different from each other, when d3 is 2 or more, two or more of groups represented by *—[W₃—(Z₃)ₑ₃] may be identical to or different from each other, when d4 is 2 or more, two or more of groups represented by *—[W₄—(Z₄)ₑ₁] may be identical to or different from each other, when d5 is 2 or more, two or more of groups represented by *—[W₅—(Z₅)ₑ₅] may be identical to or different from each other, when d6 is 2 or more, two or more of groups represented by *—[W₆—(Z₆)ₑ₆] may be identical to or different from each other, when d7 is 2 or more, two or more of groups represented by *—[W₇—(Z₇)ₑ₇] may be identical to or different from each other, and when d8 is 2 or more, two or more of groups represented by *—[W₈—(Z₈)ₑ₈] may be identical to or different from each other. In an embodiment, e1 to e8 and d1 to d8 in Formulae 1-1, 1-2, 2-1, and 2-2 may each independently be 0, 1, 2, or 3.

In Formulae 1-1, 1-2, 1-3, 2-1, 2-2, and 2-3, i) two or more of a plurality of Z₁(s), ii) two or more of a plurality of Z₂(s), iii) two or more of a plurality of Z₃(s), iv) two or more of a plurality of Z₄(s), v) two or more of a plurality of Z₅(s), vi) two or more of a plurality of Z₆(s), vii) two or more a plurality of Z₇(s), viii) two or more of a plurality of Z₈(s), ix) two or more of R₁ to R₃, and x) at least one of R₄ to R₆ may optionally be linked to each other to form a C₅-C₃₀ carbocyclic group unsubstituted or substituted with at least one R₁₀ₐ or a C₁-C₃₀ heterocyclic group unsubstituted or substituted with at least one R₁₀ₐ.

R₁₀ₐ may be as described herein in connection with Z₁.

* and *′ in Formulae 1-1, 1-2, 1-3, 2-1, 2-2, and 2-3 each indicate a binding site to Ir in Formulae 1 and 2.

The expressions “*” and “*′” used herein each indicate a binding site to a neighboring atom, unless otherwise stated.

In an embodiment, in the composition, L₁₁ of Formula 1 may be a ligand represented by Formula 1-1, L₁₂ of Formula 1 may be a ligand represented by Formula 1-2, L₂₁ of Formula 2 may be a ligand represented by Formula 2-1, L₂₂ of Formula 2 may be a ligand represented by Formula 2-2, n13 of Formula 1 may be 0, n23 of Formula 2 may be 0, and the composition may satisfy at least one of Conditions G101 to G131:

Condition G101
Ring A₁ and ring A₃ in Formulae 1-1 and 1-2 are different from each other;

Condition G102
A Y₁-containing monocyclic group in ring A₁ of Formula 1-1, a Y₂-containing monocyclic group in ring A₂ of Formula 1-1, and a Y₄-containing monocyclic group in ring A₄ of Formula 1-2 are each a 6-membered ring;

Condition G103
A Y₃-containing monocyclic group in ring A₃ of Formula 1-2 is a 6-membered ring;

Condition G104
A Y₃-containing monocyclic group in ring A₃ of Formula 1-2 is a 5-membered ring;

Condition G105

A Y₁-containing monocyclic group in ring A₁ of Formula 1-1 is a 6-membered ring, and a Y₃-containing monocyclic group in ring A₃ of Formula 1-2 is a 5-membered ring;

Condition G106

Ring A₅ and ring A₇ in Formulae 2-1 and 2-2 are identical to each other;

Condition G107

A Y₅-containing monocyclic group in ring A₅ of Formula 2-1, a Y₆-containing monocyclic group in ring A₆ of Formula 2-1, and a Y₈-containing monocyclic group in ring A₈ of Formula 2-2 are each a 6-membered ring;

Condition G108

A Y₇-containing monocyclic group in ring A₇ of Formula 2-2 is a 6-membered ring;

Condition G109

A Y₇-containing monocyclic group in ring A₇ of Formula 2-2 is a 5-membered ring;

Condition G110

A Y₅-containing monocyclic group in ring A₅ of Formula 2-1 and a Y₇-containing monocyclic group in ring A₇ of Formula 2-2 are each a 6-membered ring;

Condition G111

Ring A₁, ring A₃, ring A₅, and ring A₇ in Formulae 1-1, 1-2, 2-1, and 2-2 are each independently i) an A group, ii) a polycyclic group having 4 to 60 carbon atoms in which two or more A groups are condensed with each other, or iii) a polycyclic group having 4 to 60 carbon atoms in which at least one A group and at least one B group are condensed with each other,

the A group is a pyridine group, a pyrimidine group, a pyridazine group, a pyrazine group, or a triazine group, and

the B group is a cyclohexane group, a cyclohexene group, a norbornane group, a benzene group, a furan group, a thiophene group, a selenophene group, a pyrrole group, a cyclopentadiene group, or a silole group;

Condition G112

Ring A₃ and ring A₇ in Formulae 1-2 and 2-2 are each independently i) a C group, ii) a polycyclic group having 4 to 60 carbon atoms in which two or more C groups are condensed with each other, or iii) a polycyclic group having 4 to 60 carbon atoms in which at least one C group and at least one D group are condensed with each other,

the C group is a pyrrole group, a pyrazole group, an imidazole group, a triazole group, an oxazole group, an isoxazole group, a thiazole group, or an isothiazole group, and

the D group is a cyclohexane group, a cyclohexene group, a norbornane group, a benzene group, a furan group, a thiophene group, a selenophene group, a cyclopentadiene group, a silole group, a pyridine group, a pyrimidine group, a pyridazine group, a pyrazine group, or a triazine group;

Condition G113

Ring A₁ and ring A₅ in Formulae 1-1 and 2-1 are each independently:

a pyridine group, a pyrimidine group, a pyridazine group, or a pyrazine group; or

a pyridine group, a pyrimidine group, a pyridazine group, or a pyrazine group, each condensed with a cyclohexane group, norbornane group, a benzene group, or a combination thereof;

Condition G114

Ring A₃ and ring A₇ in Formulae 1-2 and 2-2 are each independently:

a pyridine group, a pyrimidine group, a pyridazine group, or a pyrazine group;

a pyridine group, a pyrimidine group, a pyridazine group, or a pyrazine group, each condensed with a cyclohexane group, norbornane group, a benzene group, or a combination thereof; or

an imidazole group, a benzimidazole group, a naphthoimidazole group, a phenanthrenoimidazole group, a pyridoimidazole group, an oxazole group, a benzoxazole group, a naphthooxazole group, a phenanthrenooxazole group, a pyridooxazole group, a thiazole group, a benzothiazole group, a naphthothiazole group, a phenanthrenothiazole group, or a pyridothiazole group;

Condition G115

Ring A₂ and ring A₄ in Formulae 1-1 and 1-2 are different from each other;

Condition G116

Ring A₆ and ring A₈ in Formulae 2-1 and 2-2 are different from each other; Condition G117 Ring A₂, ring A₄, ring A₆, and ring A₈ in Formulae 1-1, 1-2, 2-1, and 2-2 are each independently i) an E group, ii) a polycyclic group having 4 to 60 carbon atoms in which two or more E groups are condensed with each other, or iii) a polycyclic group having 4 to 60 carbon atoms in which at least one E group and at least one F group are condensed with each other,

the E group is a benzene group, a pyridine group, a pyrimidine group, a pyridazine group, a pyrazine group, or a triazine group, and

the F group is a furan group, a thiophene group, a selenophene group, a pyrrole group, a cyclopentadiene group, a silole group, a pyrazole group, an imidazole group, an oxazole group, a thiazole group, an isoxazole group, or an isothiazole group;

Condition G118

Ring A₂ in Formula 1-1 is a polycyclic group having 4 to 60 carbon atoms in which two or more E groups and at least one F group are condensed with each other;

Condition G119

Ring A₄ in Formula 1-2 is a polycyclic group having 4 to 60 carbon atoms in which two or more E groups and at least one F group are condensed with each other

Condition G120

Ring A₆ in Formula 2-1 is a polycyclic group having 4 to 60 carbon atoms in which two or more E groups and one or more F groups are condensed with each other;

Condition G121

Ring A₈ in Formula 2-2 is a polycyclic group having 4 to 60 carbon atoms in which two or more E groups and at least one F group are condensed with each other;

Condition G122

Ring A₂ and ring A₆ in Formulae 1-1 and 2-1 are each independently: a benzene group, a naphthalene group, a phenanthrene group, a dibenzofuran group, a dibenzothiophene group, a dibenzoselenophene group, a carbazole group, a fluorene group, or a dibenzosilole group; or

a benzene group, a naphthalene group, a phenanthrene group, a dibenzofuran group, a dibenzothiophene group, a dibenzoselenophene group, a carbazole group, a fluorene group, or a dibenzosilole group, each condensed with a cyclohexane group, a norbornane group, a benzene group, or a combination thereof;

Condition G123

Ring A₄ and ring A₈ in Formulae 1-2 and 2-2 are each independently:

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group; or

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group, each condensed with a benzene group, a pyridine group, a pyrimidine group, a pyridazine group, a pyrazine group, a cyclohexane group, a norbornane group, a furan group, a thiophene group, a selenophene group, a pyrrole group, a cyclopentadiene group, a silole group, a pyrazole group, an imidazole group, an oxazole group, a thiazole group, an isoxazole group, an isothiazole group, or a combination thereof;

Condition G124

e1 and d1 in Formula 1-1 are each not 0, and at least one of Z₁(s) are each independently a deuterated C₁-C₂₀ alkyl group, —Si(Q₃)(Q₄)(Q₅), or —Ge(Q₃)(Q₄)(Q₅) (wherein Q₃ to Q₅ are as described in the present specification);

Condition G125

e5 and d5 in Formula 2-1 are each not 0, and at least one of Z₅(s) are each independently a deuterated C₁-C₂₀ alkyl group, —Si(Q₃)(Q₄)(Q₅), or —Ge(Q₃)(Q₄)(Q₅) (wherein Q₃ to Q₅ are as described in the present specification)

Condition G126

A group represented by

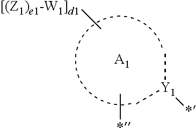

in Formula 1-1 is a group represented by one of Formulae A1-1 to A1-3;

a group represented by

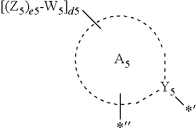

in Formula 2-1 is a group represented by one of Formulae A5-1 to A5-3; or

a group represented by

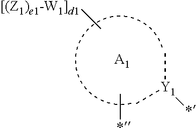

in Formula 1-1 is a group represented by one of Formulae A1-1 to A1-3, and a group represented by

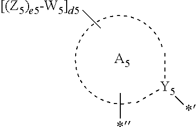

in Formula 2-1 is a group represented by one of Formulae A5-1 to A5-3:

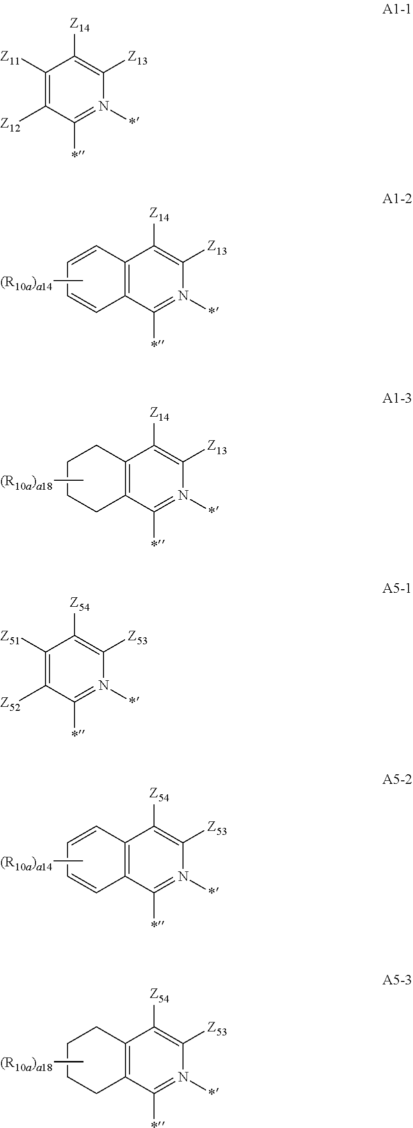

wherein, in Formulae A1-1 to A1-3 and A5-1 to A5-3,

Z₁₁ to Z₁₄ are as described in connection with Z₁,

Z₅₁ to Z₅₄ are as described in connection with Z₅,

R₁₀ₐ is as described in the present specification,

a14 may be an integer from 0 to 4,

a18 may be an integer from 0 to 8,

*′ indicates a binding site to Ir in Formulae 1 and 2, and

*″ indicates a binding site to ring A₂ or ring A₆. In an embodiment, at least one of Z₁₁, Z₁₂, and Z₁₄ (for example, Z₁₄) in Formulae A1-1 to A1-3 may be:

a C₁-C₂₀ alkyl group unsubstituted or substituted with at least one of deuterium, —F, a phenyl group, or a combination thereof;

—Si(Q₃)(Q₄)(Q₅); Or

—Ge(Q₃)(Q₄)(Q₅). In one or more embodiments, at least one of Z₅₁, Z₅₂, and Z₅₄ (for example, Z₅₄) in Formulae A5-1 to A5-3 may be:

a C₁-C₂₀ alkyl group unsubstituted or substituted with at least one of deuterium, —F, a phenyl group, or a combination thereof;

—Si(Q₃)(Q₄)(Q₅); or

—Ge(Q₃)(Q₄)(Q₅),

Condition G127

A group represented by

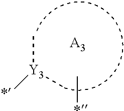

in Formula 1-2 and a group represented by

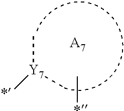

in Formula 2-2 are each independently a group represented by one of Formulae NR1 to NR48:

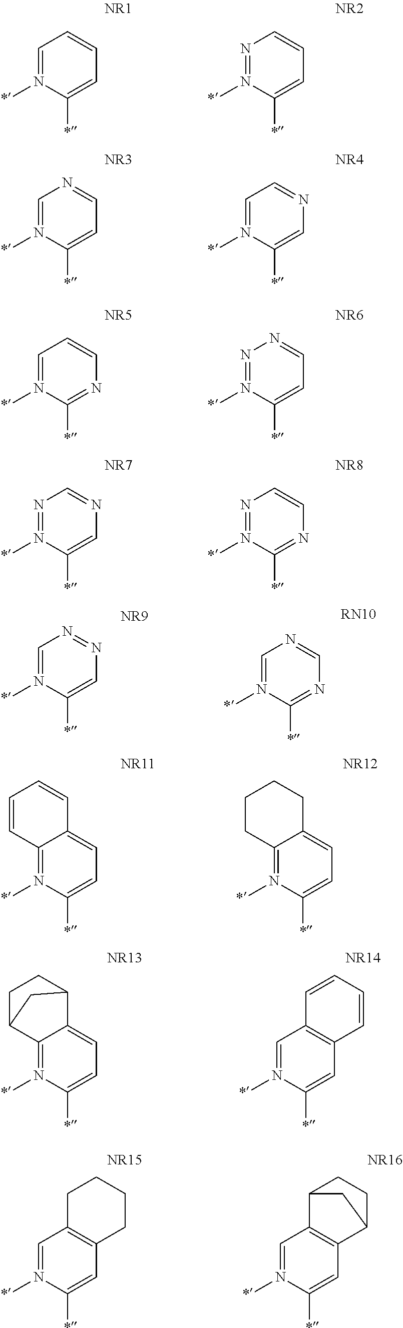

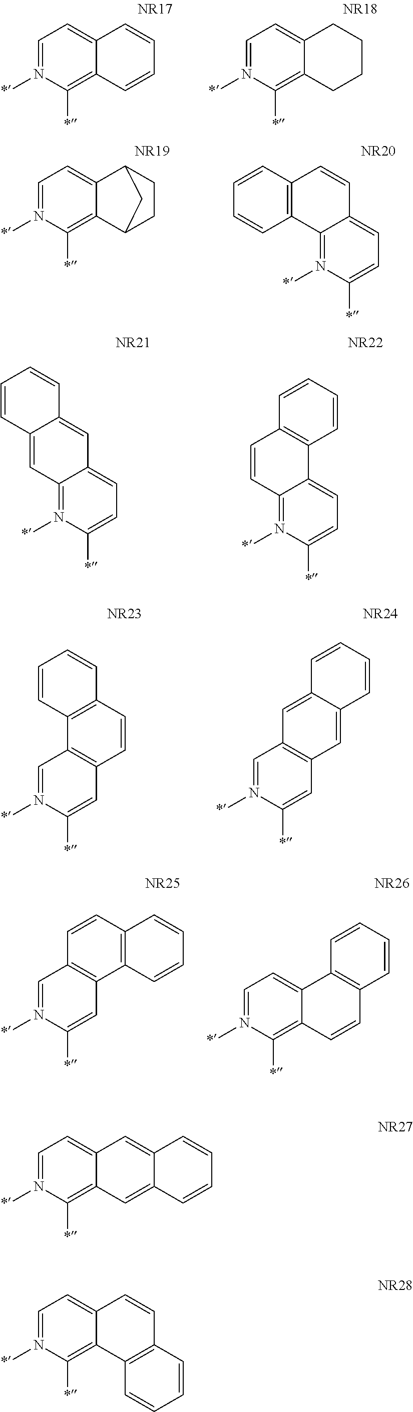

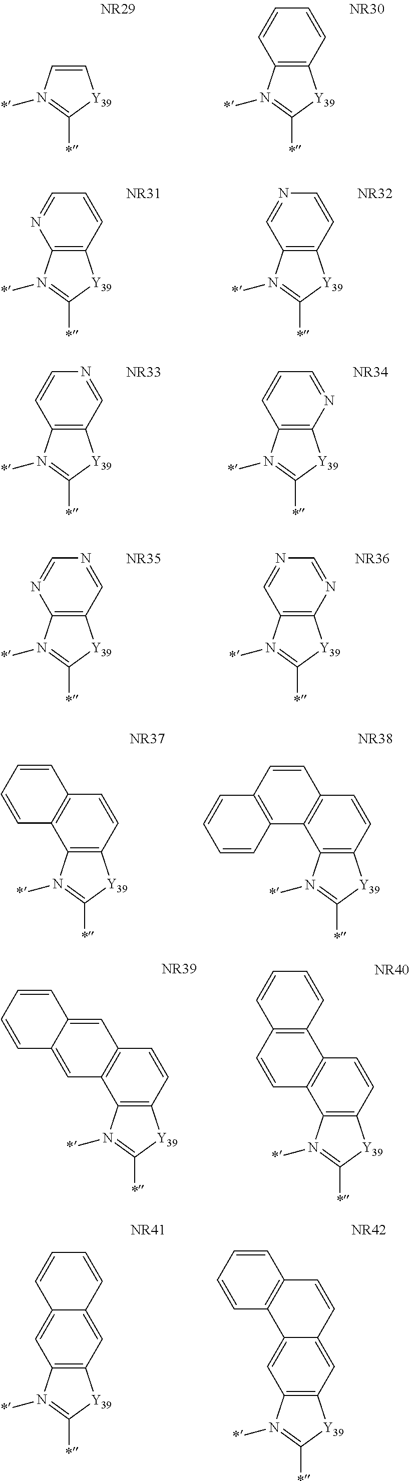

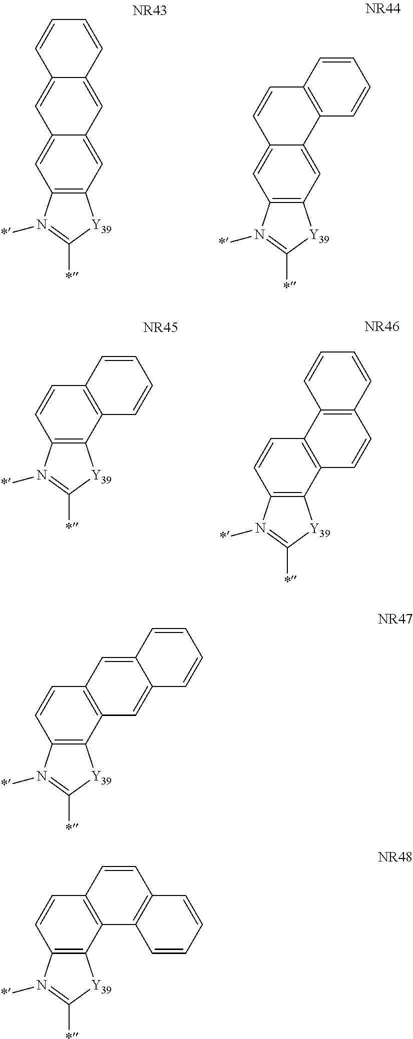

wherein, in Formulae NR1 to NR48,

Y₃₉ may be O, S, Se, N—[W₃—(Z₃)ₑ₃], N—[W₇—(Z₇)ₑ₇], C(Z₃₉ₐ)(Z_{39b}), C(Z₇₉ₐ)(Z_{79b}), Si(Z₃₉ₐ)(Z_{39b}), or Si(Z₇₉ₐ)(Z_{79b}),

W₃, W₇, Z₃, Z₇, e3, and e7 are as described in the present specification, Z₃₉ₐ and Z_{39b} are as described in connection with Z₃, and Z₇₉ₐ and Z_{79b} are as described in connection with Z₇,

*′ indicates a binding site to Ir in Formula 1 or Formula 2, and

*″ indicates a binding site to ring A₄ or ring A₈;

Condition G128

A group represented by

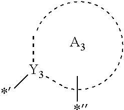

in Formula 1-2 is a group represented by one of Formulae NR30 to NR48;

Condition G129

A group represented by

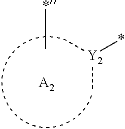

in Formula 1-1, a group represented by

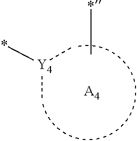

in Formula 1-2, a group represented by

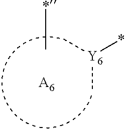

in Formula 2-1, and a group represented by

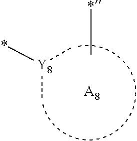

in Formula 2-2 are each independently a group represented by one of Formulae CR1 to CR29:

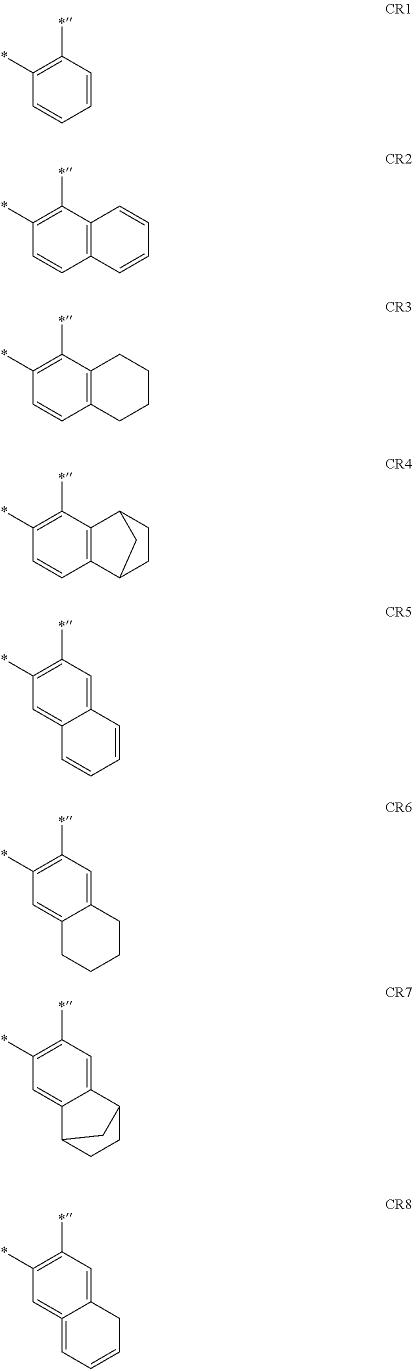

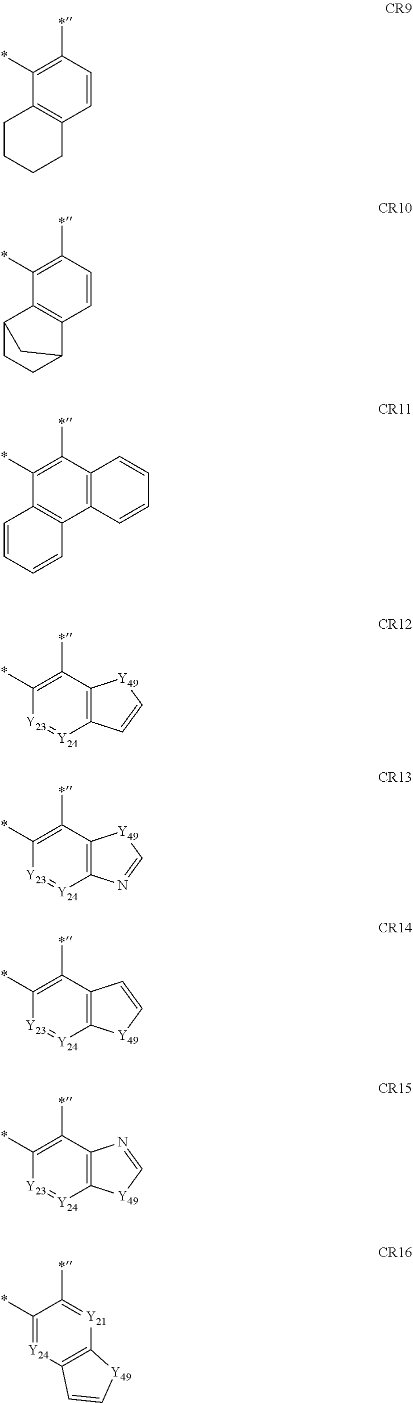

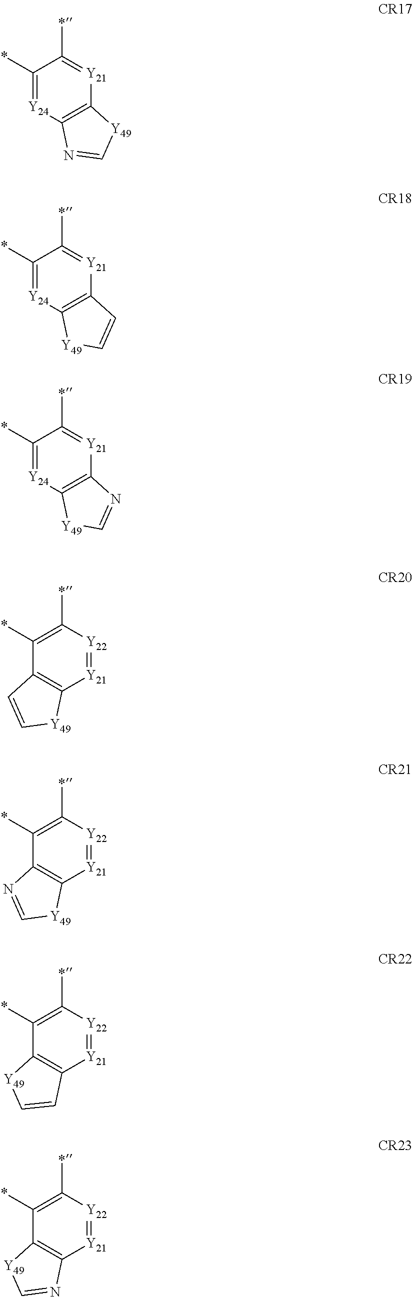

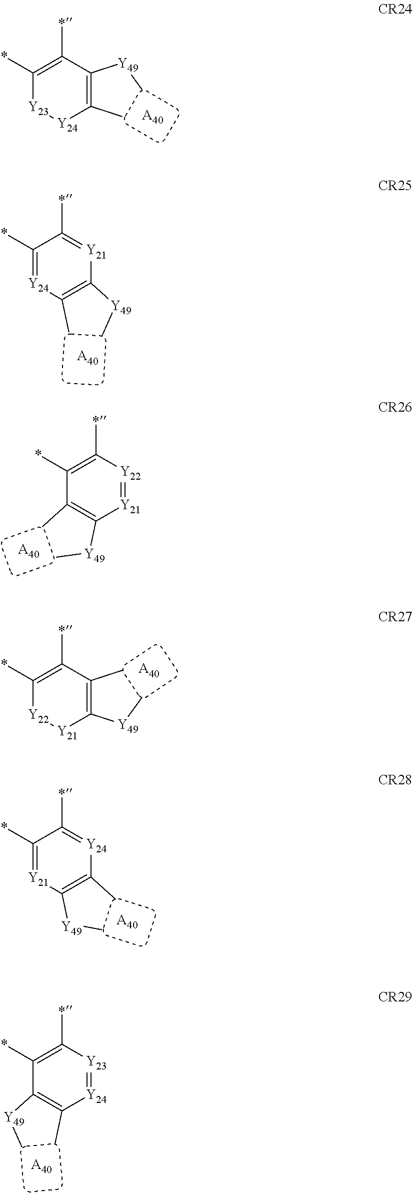

wherein, in Formulae CR1 to CR29, Y₄₉ may be O, S, Se, N—[W₂—(Z₂)ₑ₂], N—[W₄—(Z₄)ₑ₄], N—[W₆—(Z₆)ₑ₆], N—[W₈—(Z₈)ₑ₈], C(Z₂₉ₐ)(Z_{29b}), C(Z₄₉ₐ)(Z_{49b}), C(Z₆₉ₐ)(Z_{69b}), C(Z₈₉ₐ)(Z_{89b}), Si(Z₂₉ₐ)(Z_{29b}), Si(Z₄₉ₐ)(Z_{49b}), Si(Z₆₉ₐ)(Z_{69b}), or Si(Z₈₉ₐ)(Z_{89b}),

W₂, W₄, W₆, W₈, Z₂, Z₄, Z₆, Z₈, e2, e4, e6, and e8 are as described in the present specification, Z₂₉ₐ and Z_{29b} are described in connection with Z₂, Z₄₉ₐ and Z_{49b} are as described in connection with Z₄, Z₆₉ₐ and Z_{69b} are as described in connection with Z₆, and Z₈₉ₐ and Z₈₉b are as described in connection with Z₈,

Y₂₁ to Y₂₄ may each independently be N or C,

ring A₄₀ may be a C₅-C₃₀ carbocyclic group or a C₁-C₃₀ heterocyclic group (for example, a benzene group, a naphthalene group, a phenanthrene group, a pyridine group, a pyrimidine group, a pyrazine group, a pyridazine group, a quinoline group, an isoquinoline group, a benzoquinoline group, a benzoisoquinoline group, a quinoxaline group, a benzoquinoxaline group, a quinazoline group, or a benzoquinazoline group),

* indicates a binding site to Ir in Formulae 1 and 2, and

*″ indicates a binding site to ring A₁, ring A₃, ring A₅, and ring A₇;

Condition G130

λP(Ir1) and λP(Ir2) are each in a range of about 500 nm to about 570 nm;

Condition G131

Expression 1 is satisfied, and
i) λP(Ir1) is in a range of about 520 nm to about 540 nm, and λP(Ir2) is in a range of about 500 nm to about 530 nm, or ii) λP(Ir1) is in a range of about 550 nm to about 570 nm, and λP(Ir2) is in a range of about 540 nm to about 560 nm;

In an embodiment, in the composition, L₁₁ of Formula 1 may be a ligand represented by Formula 1-1, L₁₂ of Formula 1 may be a ligand represented by Formula 1-3, L₂₁ of Formula 2 may be a ligand represented by Formula 2-1, L₂₂ of Formula 2 may be a ligand represented by Formula 2-3, n13 of Formula 1 may be 0, n23 of Formula 2 may be 0, and the composition may satisfy at least one of Conditions R101 to R123:

Condition Rb 101

A Y₁-containing monocyclic group in ring A₁ and a Y₂-containing monocyclic group in ring A₂ of Formula 1-1 are each a 6-membered ring;

Condition R102

A Y₅-containing monocyclic group in ring A₅ and a Y₆-containing monocyclic group in ring A₆ of Formula 2-1 are each a 6-membered ring;

Condition R103

Ring A₁ of Formula 1-1 is a polycyclic group having 4 to 60 carbon atoms in which three or more rings are condensed;

Condition R104

Ring A₅ of Formula 2-1 is a polycyclic group having 4 to 60 carbon atoms in which two or more rings are condensed;

Condition R105

Ring A₁ of Formula 1-1 and ring A₅ of Formula 2-1 are each a polycyclic group having 4 to 6 carbon atoms in which two or more rings are condensed, and the number of rings condensed in ring A₁ is greater than the number of rings condensed in ring A₅; Condition R106 Ring A₁ and ring A₅ in Formulae 1-1 and 2-1 are each independently: i) a polycyclic group having 4 to 60 carbon atoms in which at least one A group and at least one benzene group are condensed with each other; ii) a polycyclic group having 4 to 60 carbon atoms in which at least one A group and at least one G group are condensed with each other; or iii) a polycyclic group having 4 to 60 carbon atoms in which at least one A group, at least one benzene group, and at least one G group are condensed with each other,

the A group is a pyridine group, a pyrimidine group, a pyridazine group, a pyrazine group, or a triazine group, and

the G group is a cyclohexane group, a cyclohexene group, norbornane group, a furan group, a thiophene group, a selenophene group, a pyrrole group, a cyclopentadiene group, or a silole group;

Condition R107

Ring A₁ and ring A₅ in Formulae 1-1 and 2-1 are each independently:

a quinoline group, an isoquinoline group, a quinoxaline group, a quinazoline group, a benzoquinoline group, a benzoisoquinoline group, a benzoquinoxaline group, a benzoquinazoline group, a phenanthroline group, or a phenanthridine group; or

a quinoline group, an isoquinoline group, a quinoxaline group, a quinazoline group, a benzoquinoline group, a benzoisoquinoline group, a benzoquinoxaline group, a benzoquinazoline group, a phenanthroline group, or a phenanthridine group, each condensed with a cyclohexane group, a norbornane group, a benzene group, a pyridine group, a pyrimidine group, or a combination thereof;

Condition R108

Ring A₂ and ring A₆ in Formulae 1-1 and 2-1 are each independently i) an E group, ii) a polycyclic group having 4 to 60 carbon atoms in which two or more E groups are condensed with each other, or iii) a polycyclic group having 4 to 60 carbon atoms in which at least one E group and at least one F group are condensed with each other, wherein the E group and the F group are as described in the present specification;

Condition R109

Ring A₂ and ring A₆ in Formulae 1-1 and 2-1 are each independently:

a benzene group, a naphthalene group, a phenanthrene group, a dibenzofuran group, a dibenzothiophene group, a dibenzoselenophene group, a carbazole group, a fluorene group, or a dibenzosilole group; or

a benzene group, a naphthalene group, a phenanthrene group, a dibenzofuran group, a dibenzothiophene group, a dibenzoselenophene group, a carbazole group, a fluorene group, or a dibenzosilole group, each condensed with a cyclohexane group, a norbornane group, a benzene group, or a combination thereof;

Condition R110

In Formula 1-1, e1 and d1 are each not 0, and at least one of Z₅(s) are each independently deuterium, —F, a C₁-C₂₀ alkyl group, a C₃-C₁₀ cycloalkyl group, a phenyl group, a biphenyl group, a deuterated C₁-C₂₀ alkyl group, a deuterated C₃-C₁₀ cycloalkyl group, a deuterated phenyl group, a deuterated biphenyl group, a fluorinated C₁-C₂₀ alkyl group, a fluorinated C₃-C₁₀ cycloalkyl group, a fluorinated phenyl group, a fluorinated biphenyl group, —Si(Q₃)(Q₄)(Q₅), or —Ge(Q₃)(Q₄)(Q₅) (wherein O₃ to O₅ are as described in the present specification);

Condition R111

In Formula 2-1, e5 and d5 are each not 0, and at least one of Z₅(s) are each independently deuterium, —F, a C₁-C₂₀ alkyl group, a C₃-C₁₀ cycloalkyl group, a phenyl group, a biphenyl group, a deuterated C₁-C₂₀ alkyl group, a deuterated C₃-C₁₀ cycloalkyl group, a deuterated phenyl group, a deuterated biphenyl group, a fluorinated C₁-C₂₀ alkyl group, a fluorinated C₃-C₁₀ cycloalkyl group, a fluorinated phenyl group, a fluorinated biphenyl group, —Si(Q₃)(Q₄)(Q₅), or —Ge(Q₃)(Q₄)(Q₅) (wherein O₃ to O₅ are as described in the present specification);

Condition R112

A group represented by

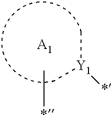

in Formula 1-1 and a group represented by

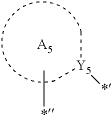

by in Formula 2-1 are each independently a group represented by one of Formulae NR(1) to NR(16):

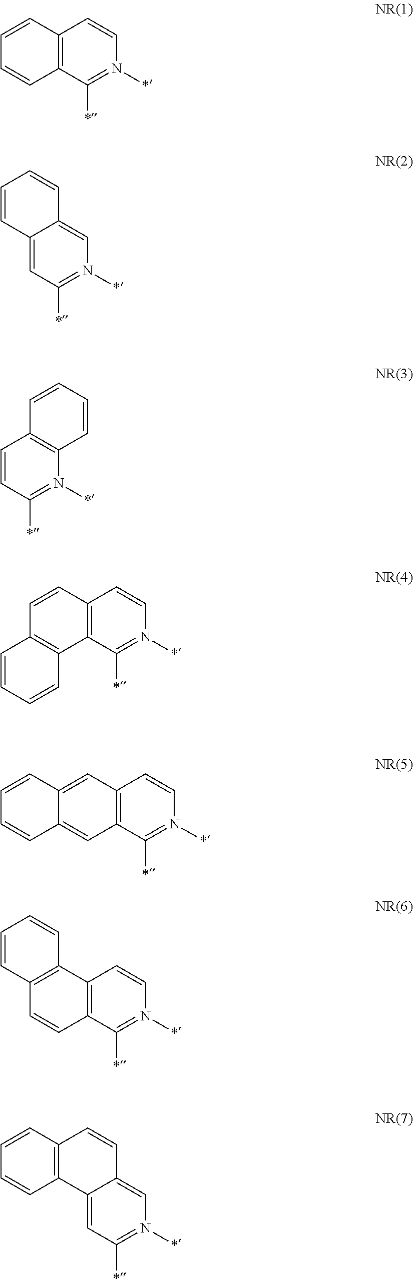

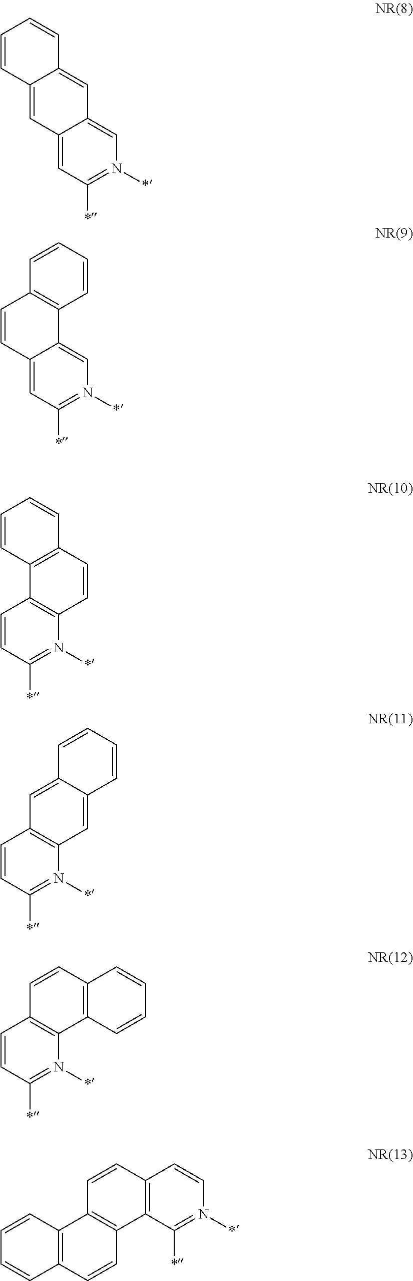

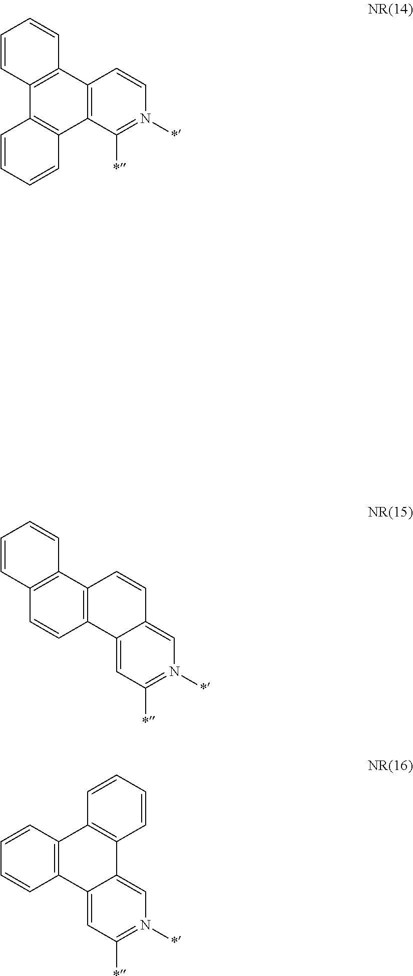

wherein, in Formulae NR(1) to NR(16),

*′ indicates a binding to Ir in Formulae 1 and 2, and

*″ indicates a binding site to ring A₂ or ring A₆.

Condition R113

A group represented by

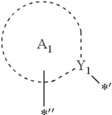

in Formula 1-1 is a group represented by one of Formulae NR(4) to NR(16);

Condition R114

A group represented by

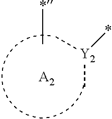

in Formula 1-1 and a group represented by

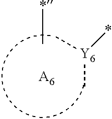

in Formula 2-1 are each independently a group represented by one of Formulae CR1 to CR29;

Condition R115

A group represented by

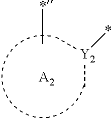

in Formula 1-1 and a group represented by

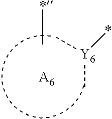

in Formula 2-1 are each independently a group represented by one of Formulae CR1 to CR11;

Condition R116

R₁ in Formula 1-3 is a group represented by *—C(R₁₁)(R₁₂)(R₁₃), and

R₁₁ to R₁₃ are each independently a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R117

R₁ in Formula 1-3 is a group represented by *—C(R₁₁)(R₁₂)(R₁₃), and

At least one of R₁₁ to R₁₃ are each independently a C₂-C₂₀ alkyl group, a deuterated C₂-C₂₀ alkyl group, a fluorinated C₂-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R118

R₁ in Formula 1-3 is a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R119

R₂ in Formula 1-3 is a group represented by *—C(R₂₁)(R₂₂)(R₂₃), and

R₂₁ to R₂₃ are each independently a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R120

R₂ in Formula 1-3 is a group represented by *—C(R₂₁)(R₂₂)(R₂₃), and

at least one of R₂₁ to R₂₃ are each independently a C₂-C₂₀ alkyl group, a deuterated C₂-C₂₀ alkyl group, a fluorinated C₂-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R121

R₂ in Formula 1-3 is a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, or a (C₁-C₂₀ alkyl)biphenyl group;

Condition R122

λP(Ir1) and λP(Ir2) are each in a range of about 570 nm to about 650 nm; Condition Rb 123

Expression 1 is satisfied, λP(Ir1) is in a range of about 620 nm to about 650 nm, and λP(Ir2) is in a range of about 570 nm to about 630 nm.

In an embodiment, Q₃ to Q₅ in Conditions G124, G125, R110, and R111 may each independently be:
a C₁-C₆₀ alkyl group unsubstituted or substituted with at least one deuterium, a C₁-C₆₀ alkyl group, a C₆-C₆₀ aryl group, or a combination thereof; or
a C₆-C₆₀ aryl group unsubstituted or substituted with at least one of deuterium, a C₁-C₆₀ alkyl group, a C₆-C₆₀ aryl group, or a combination thereof.

In one or more embodiments, Q₃ to Q₅ in Conditions G124, G125, R110, and R111 may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

In one or more embodiments, Q₃ to Q₅ in Conditions G124, G125, R110, and R111 may be identical to each other.

In one or more embodiments, two or more of Q₃ to Q₅ in Conditions G124, G125, R110, and R111 may be different from each other.

In one or more embodiments, a group represented by

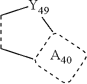

in Formulae CR24 to CR29 of Condition G129 may be a group represented by one of Formulae CR(1) to CR(13):

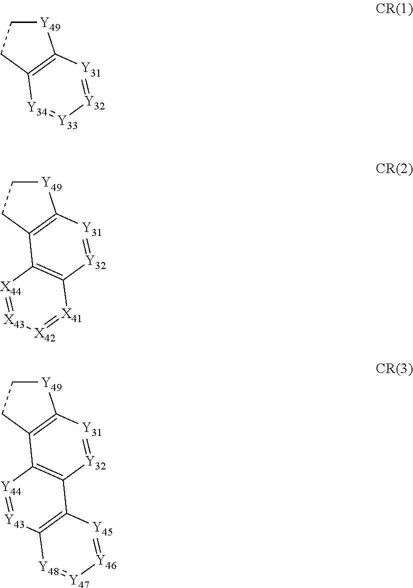

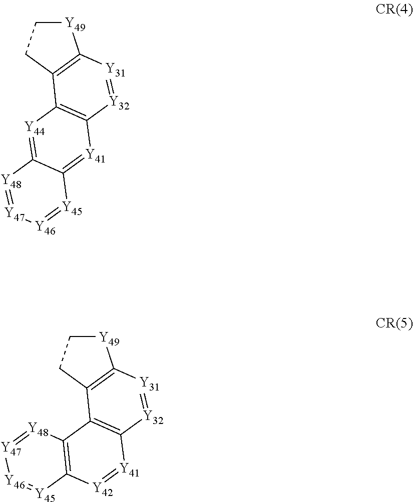

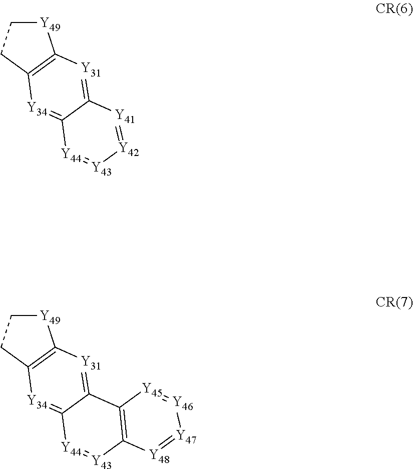

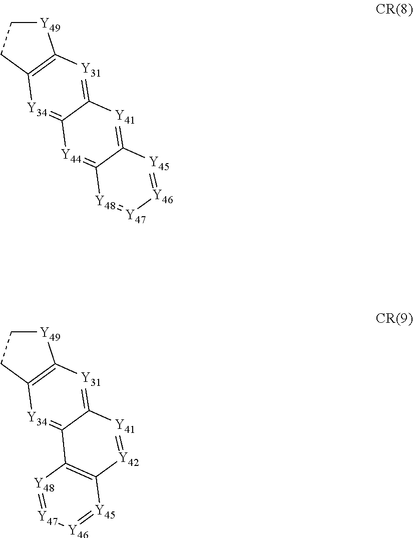

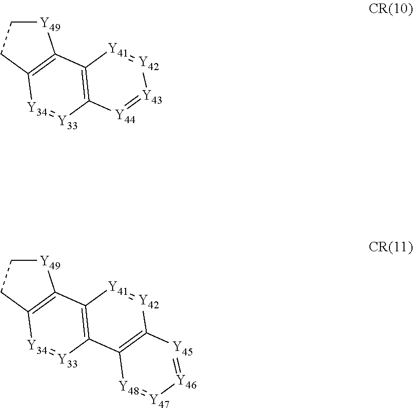

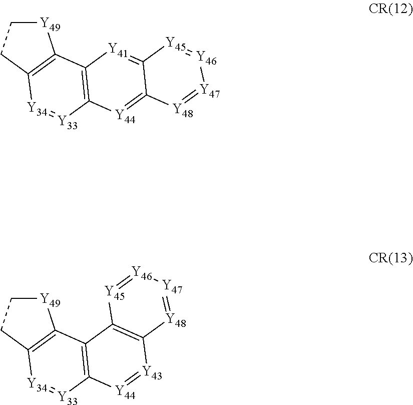

wherein, in Formulae CR(1) to CR(13),

Y₄₉ is as described in the present specification, and

Y₃₁ to Y₃₄ and Y₄₁ to Y₄₈ may each independently be C or N.

In the expressions “the composition may satisfy at least one of Conditions G101 to G131” and “the composition may satisfy at least one of Conditions R₁₀₁ to R₁₂₃” as used herein, a case in which two or more incompatible conditions are simultaneously satisfied is excluded, which may be easily understood by one of ordinary skill in the art. For example, since Conditions G103 and G104 correspond to incompatible conditions, a case in which Conditions G103 and G104 are simultaneously satisfied is excluded from the expression “the composition may satisfy at least one of Conditions G101 to G131” as used herein.

In one or more embodiments, the first compound may include at least one deuterium.

In one or more embodiments, the second compound may include at least one deuterium.

In one or more embodiments, a weight ratio of the first compound to the second compound in the composition may be in a range of about 90:10 to about 10:90, about 80:20 to about 20:80, about 70:30 to about 30:70, or about 60:40 to about 40:60.

In one or more embodiments, the weight ratio of the first compound to the second compound in the composition may be about 50:50, that is, 1:1.

In one or more embodiments, the first compound and the second compound may each independently be one of compounds of Groups G1-1 to G1-8:

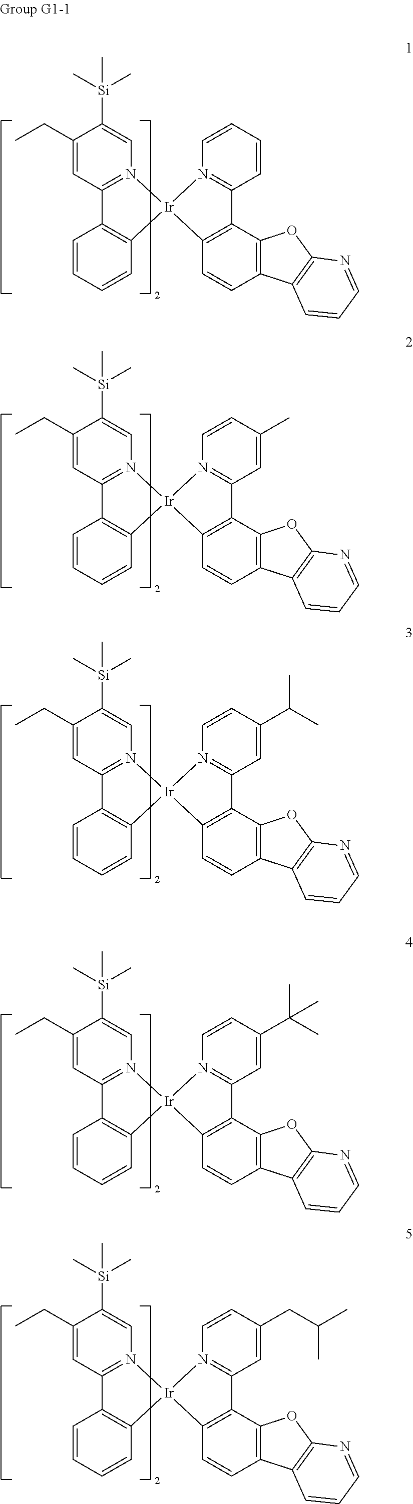

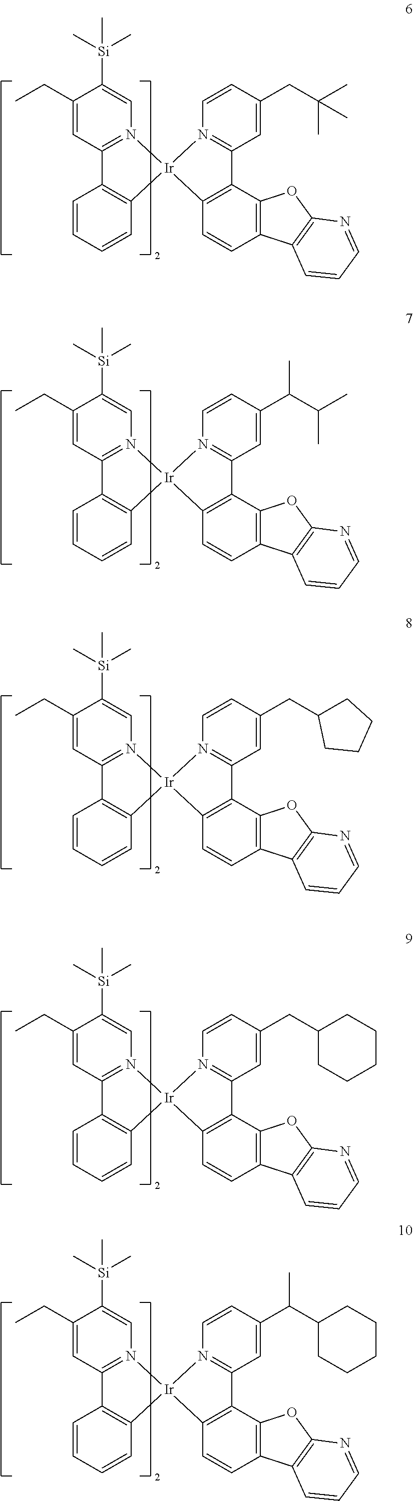

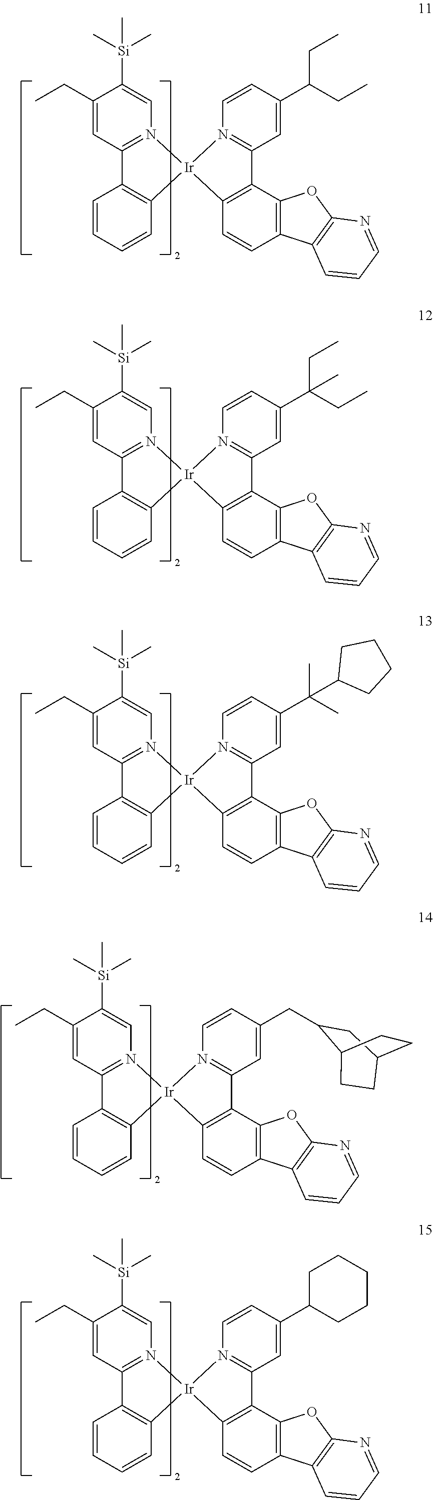

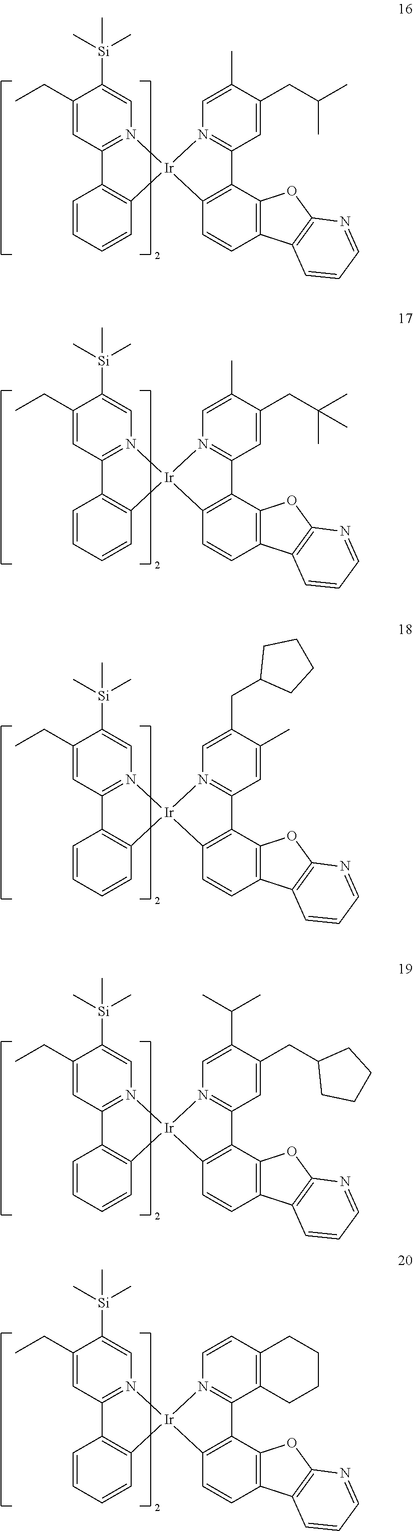

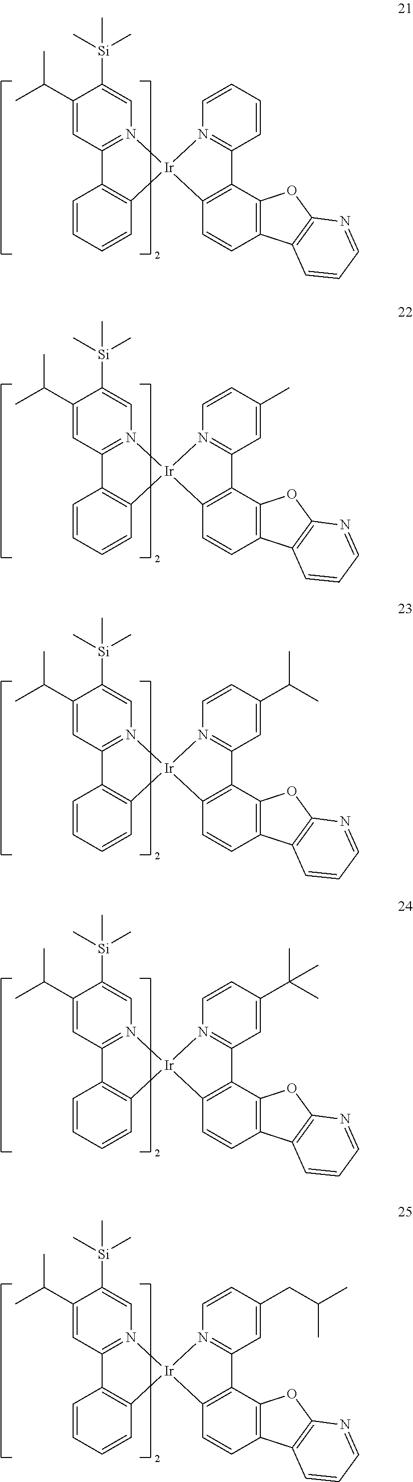

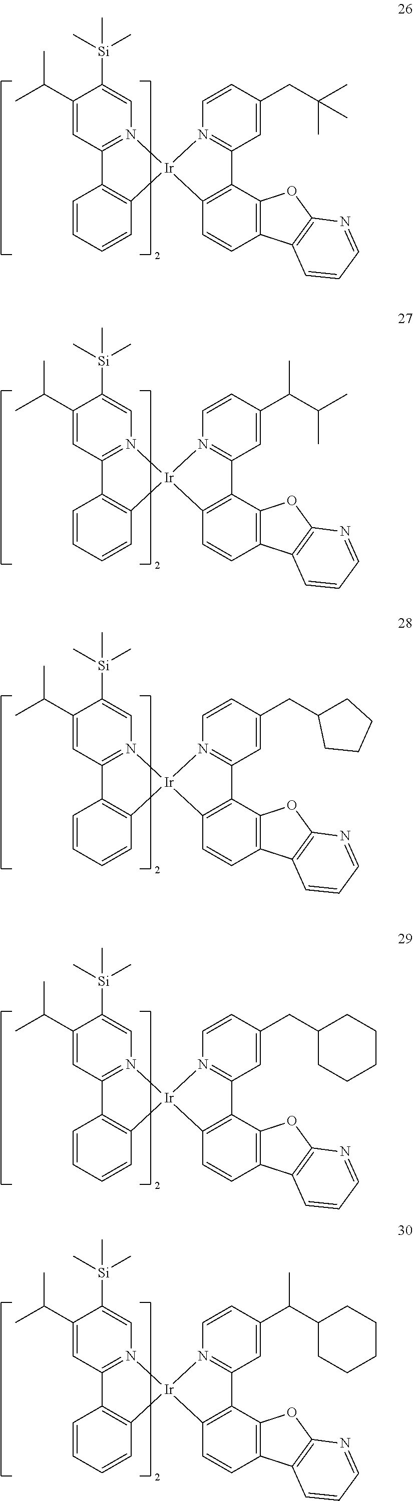

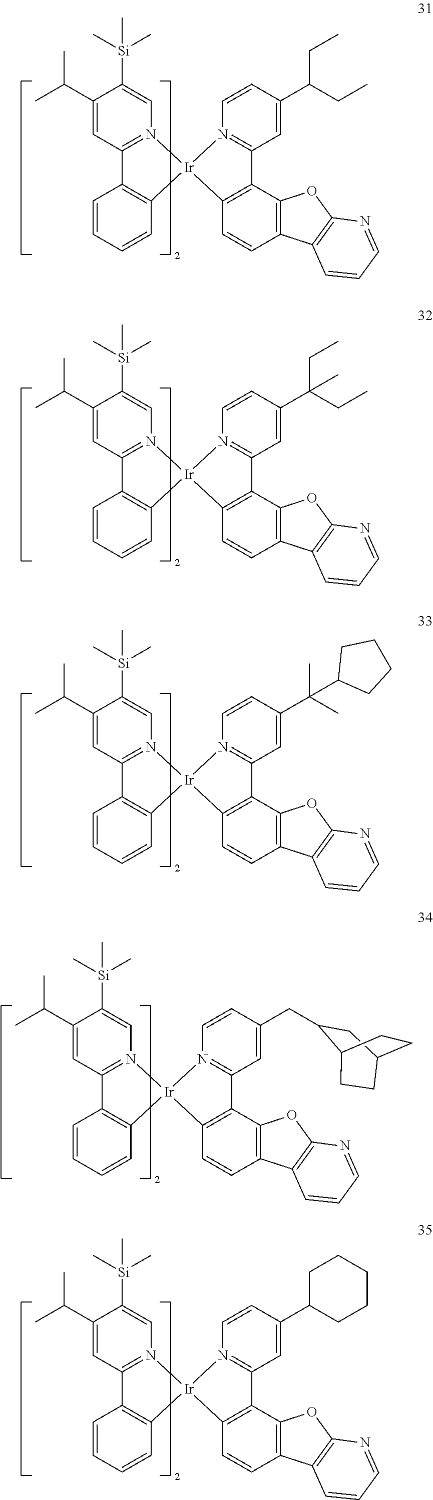

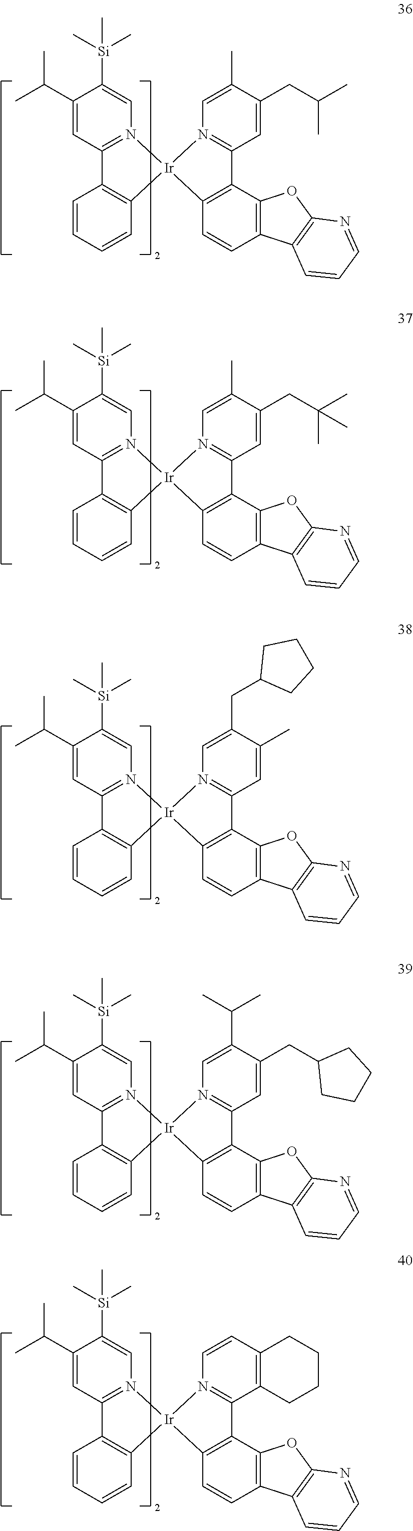

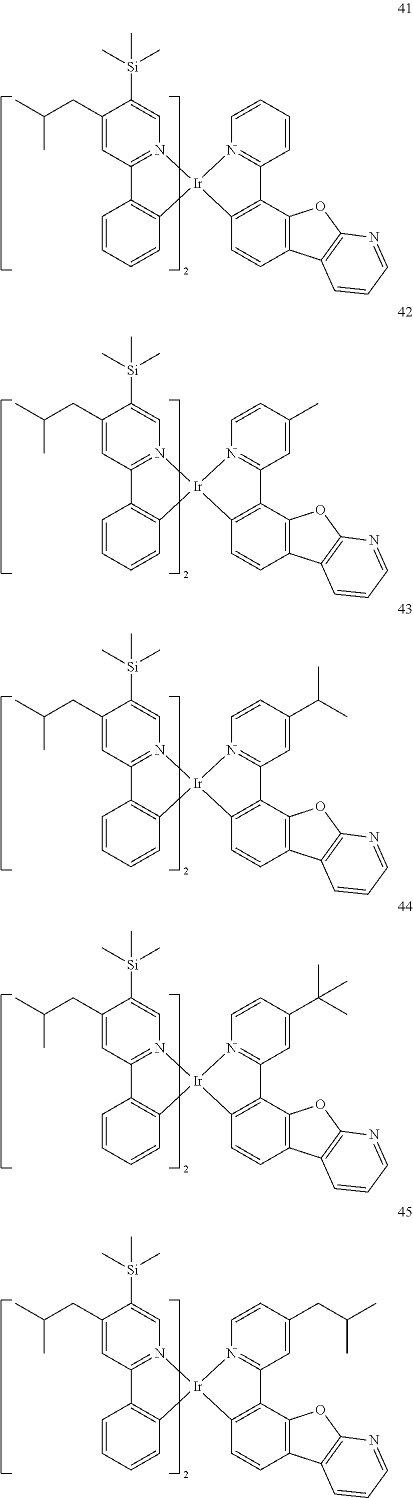

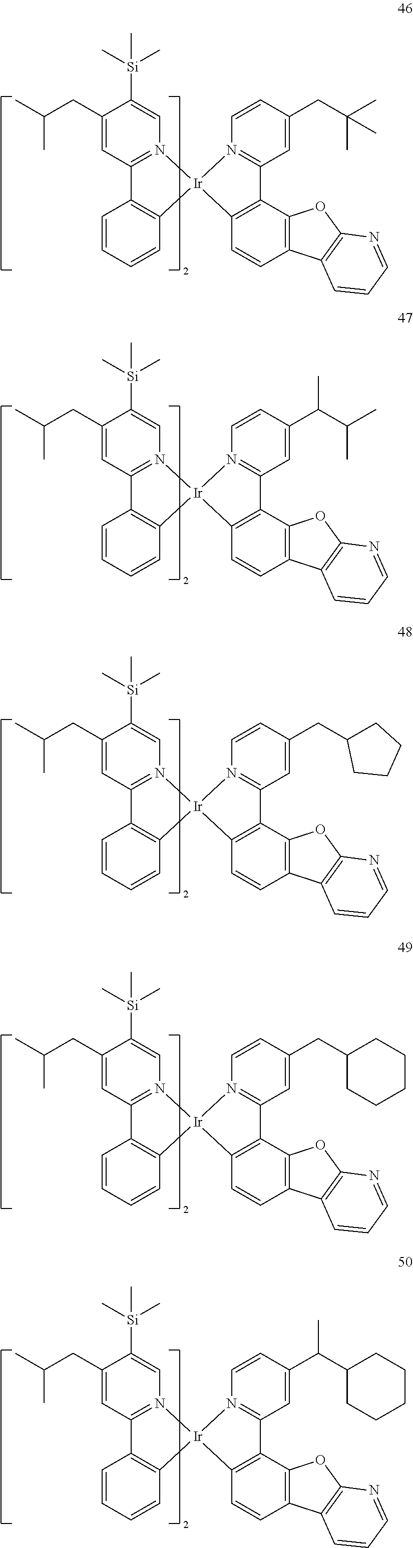

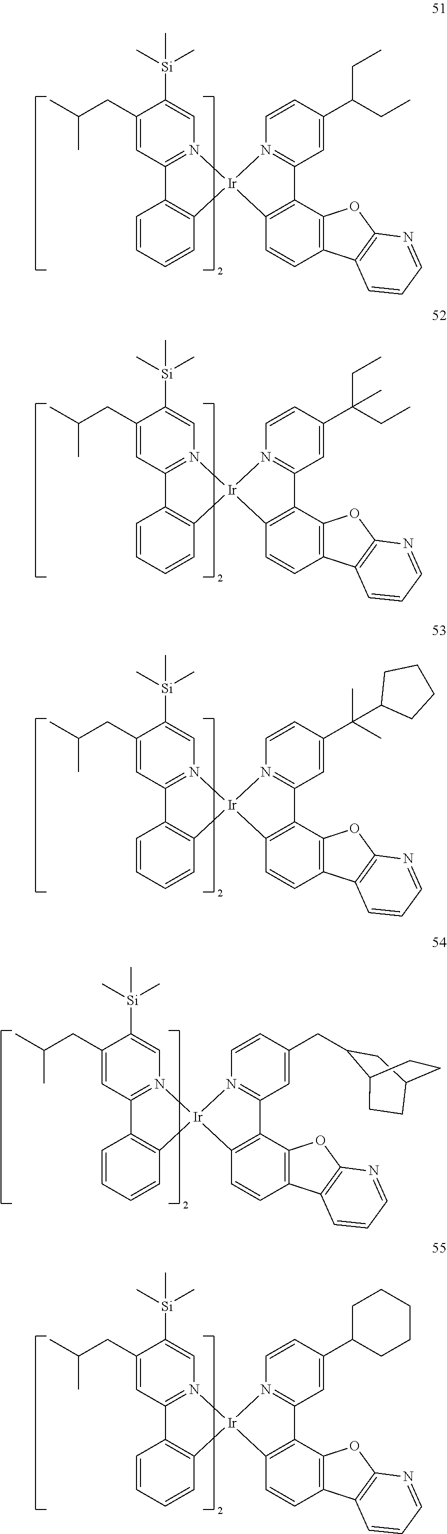

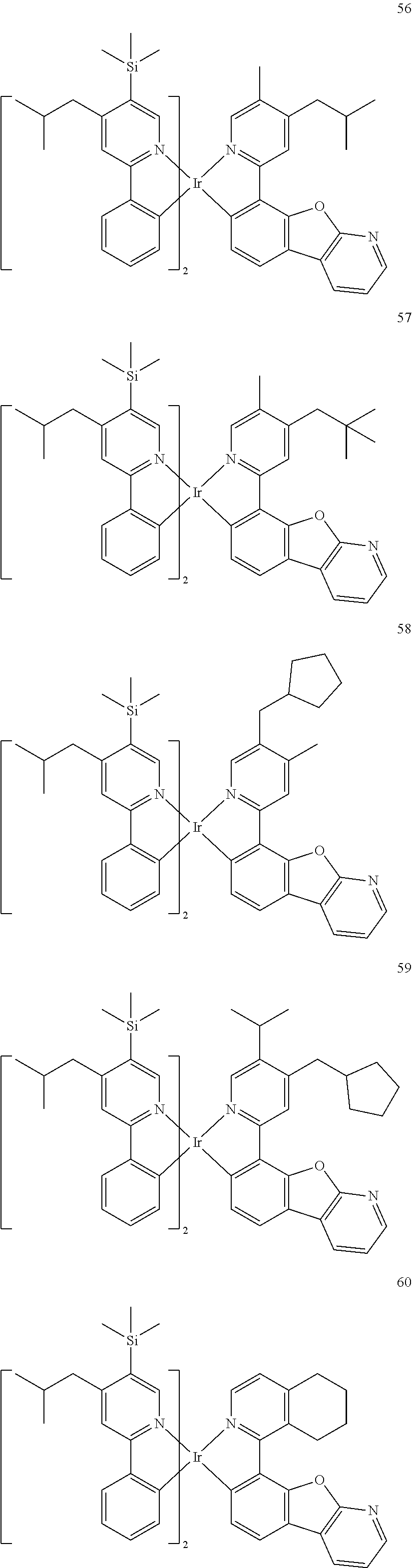

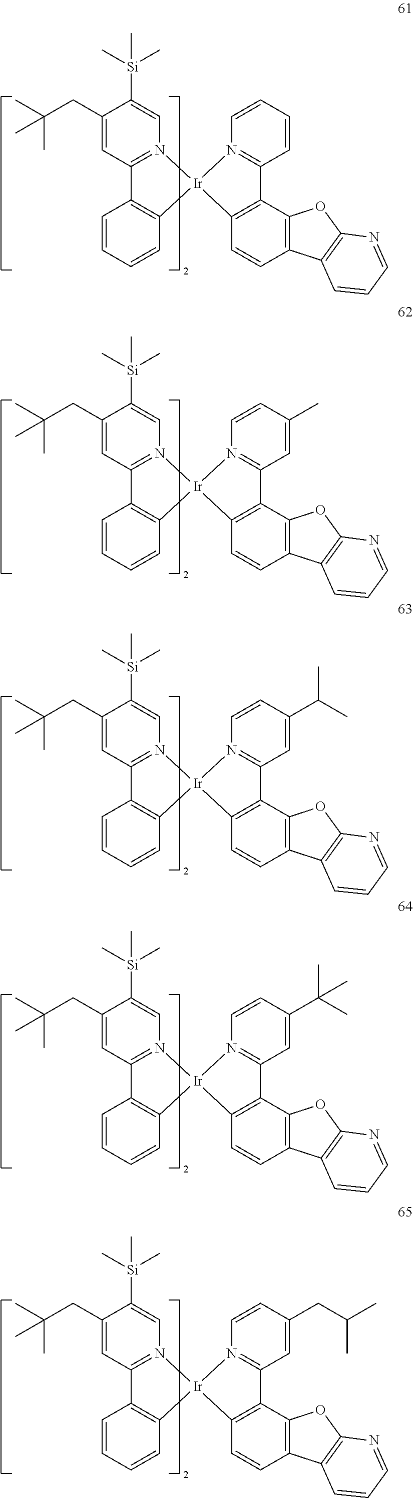

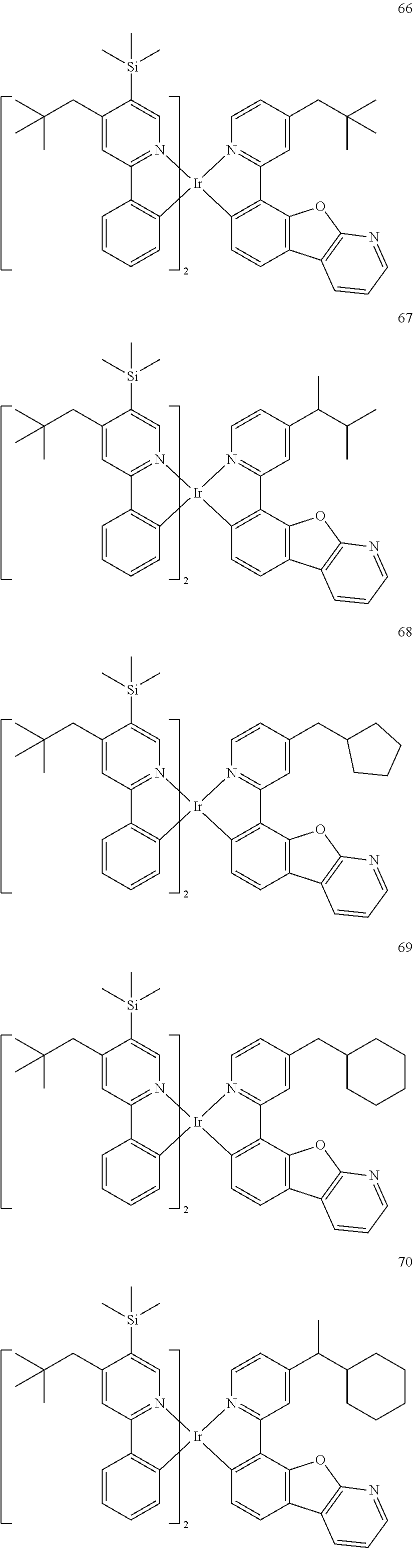

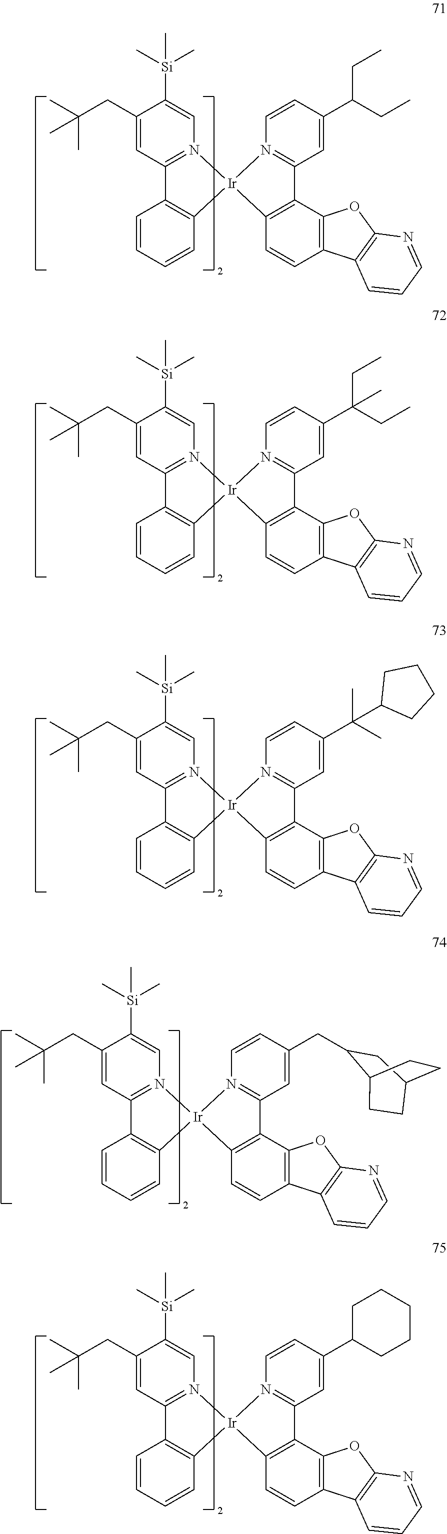

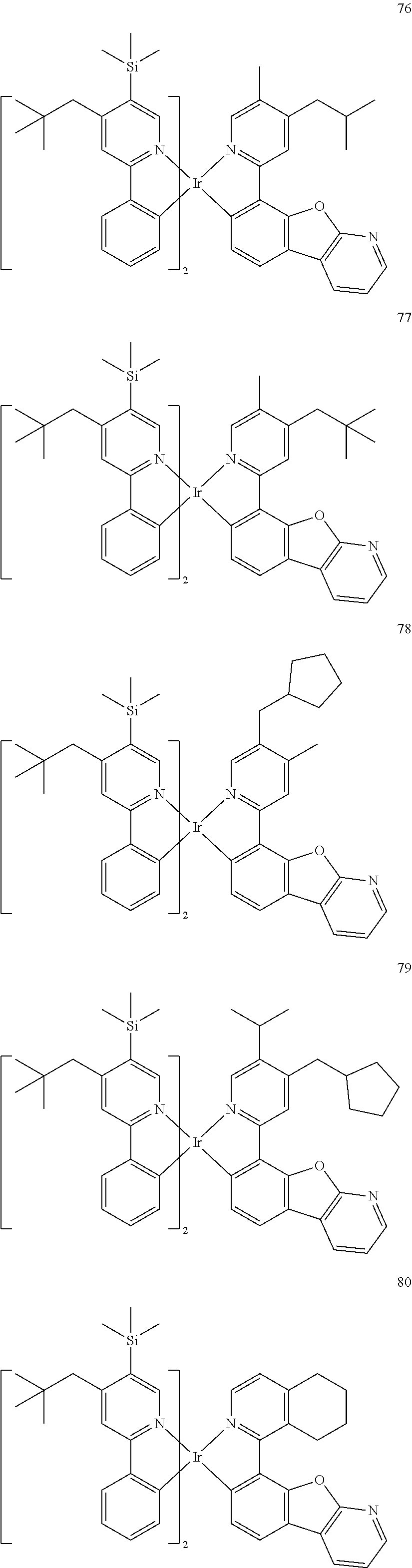

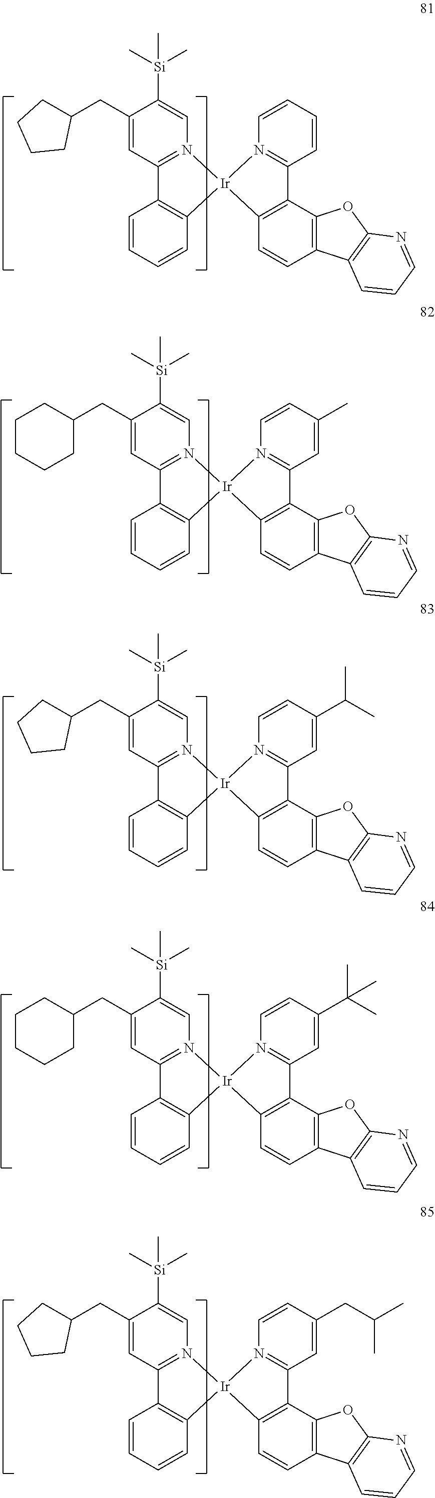

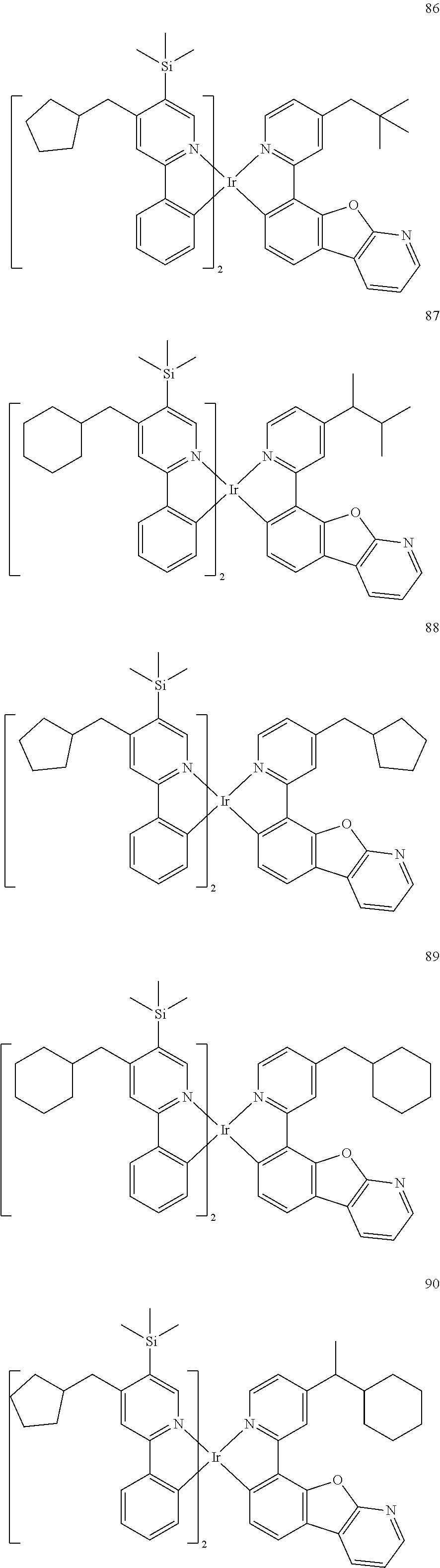

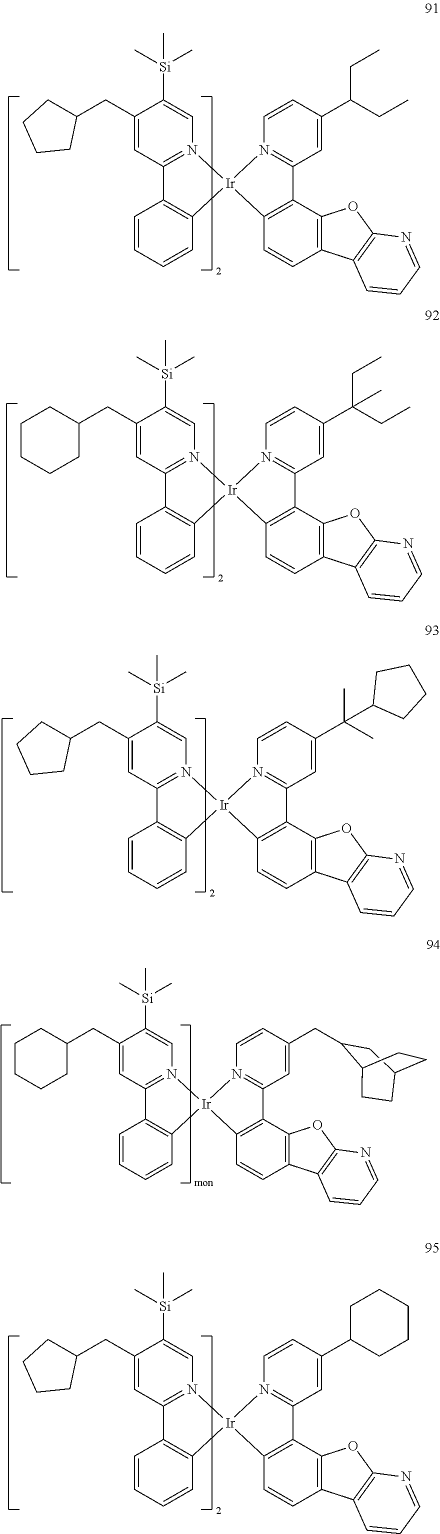

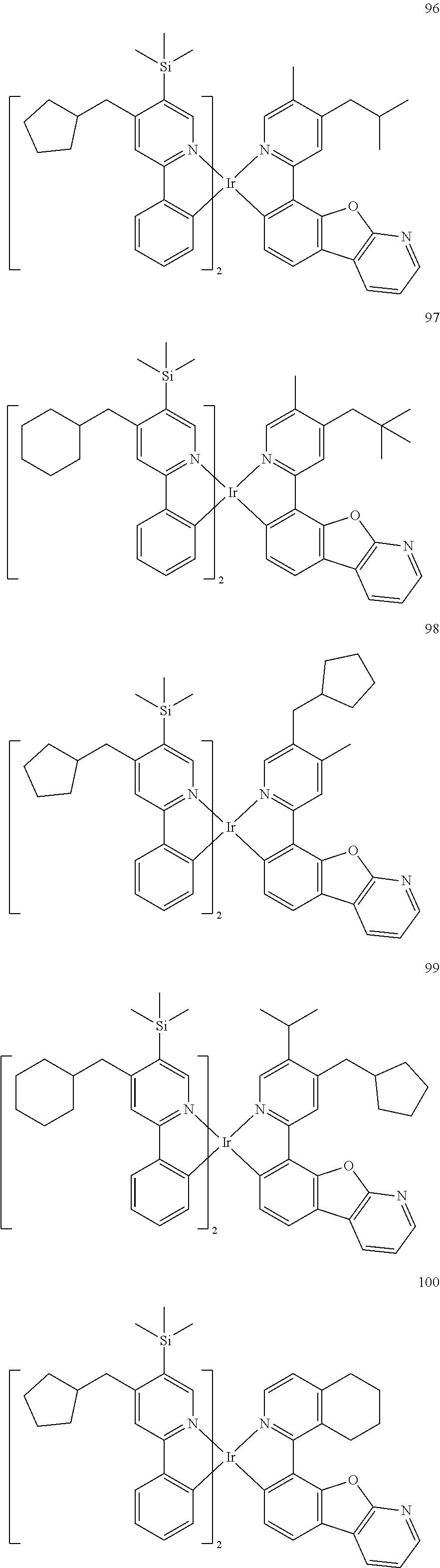

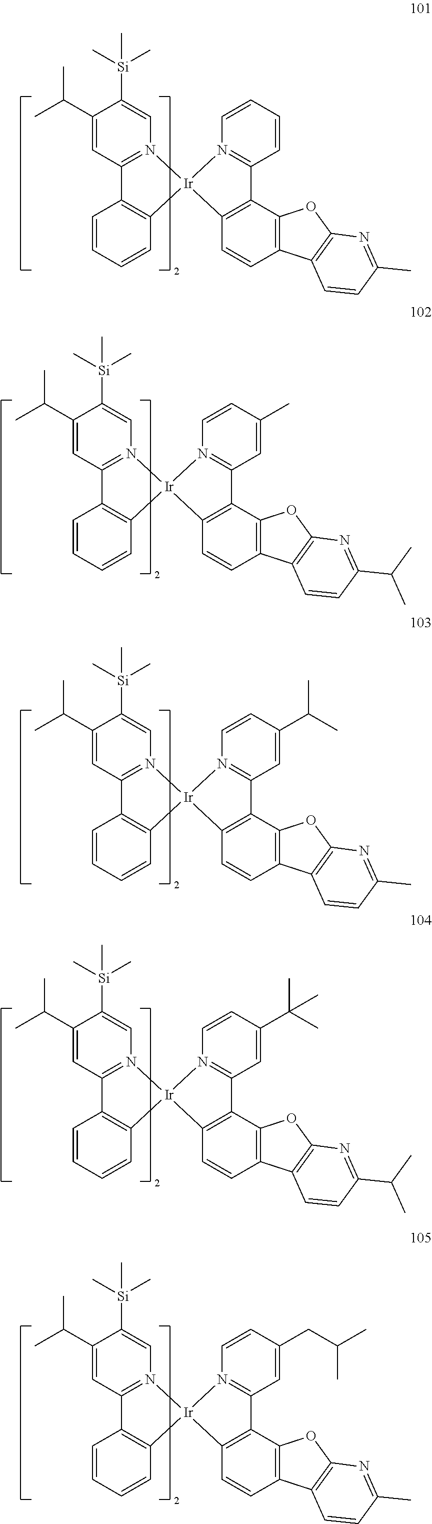

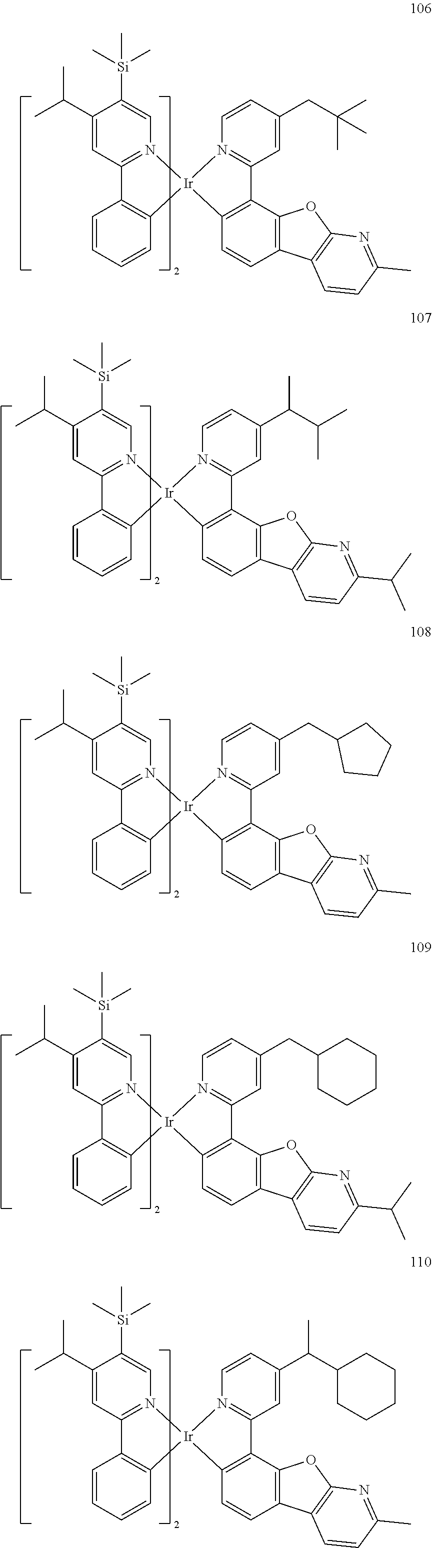

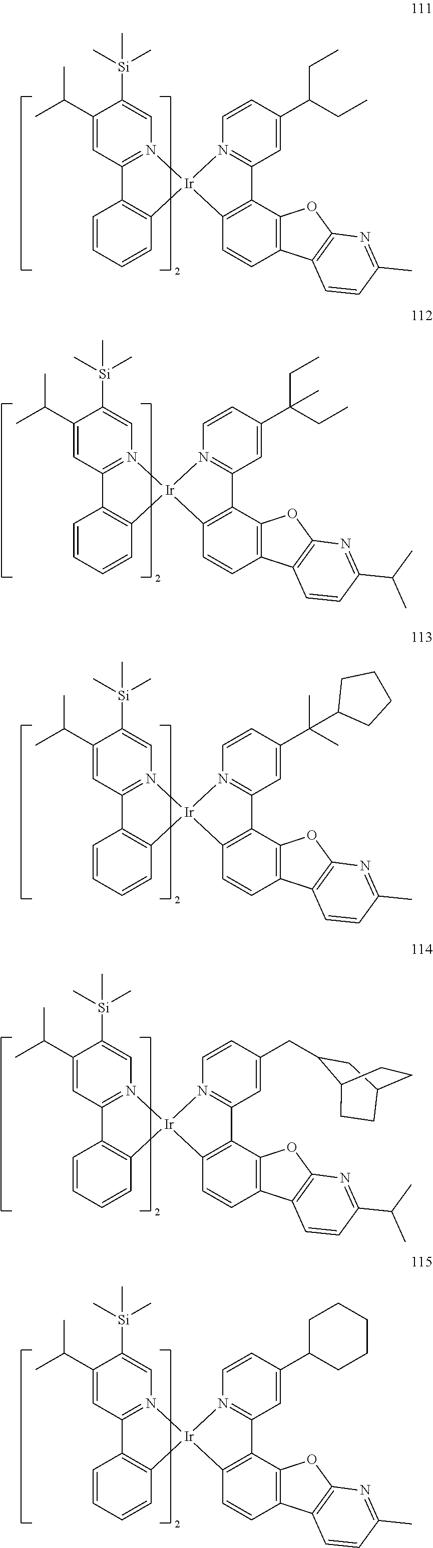

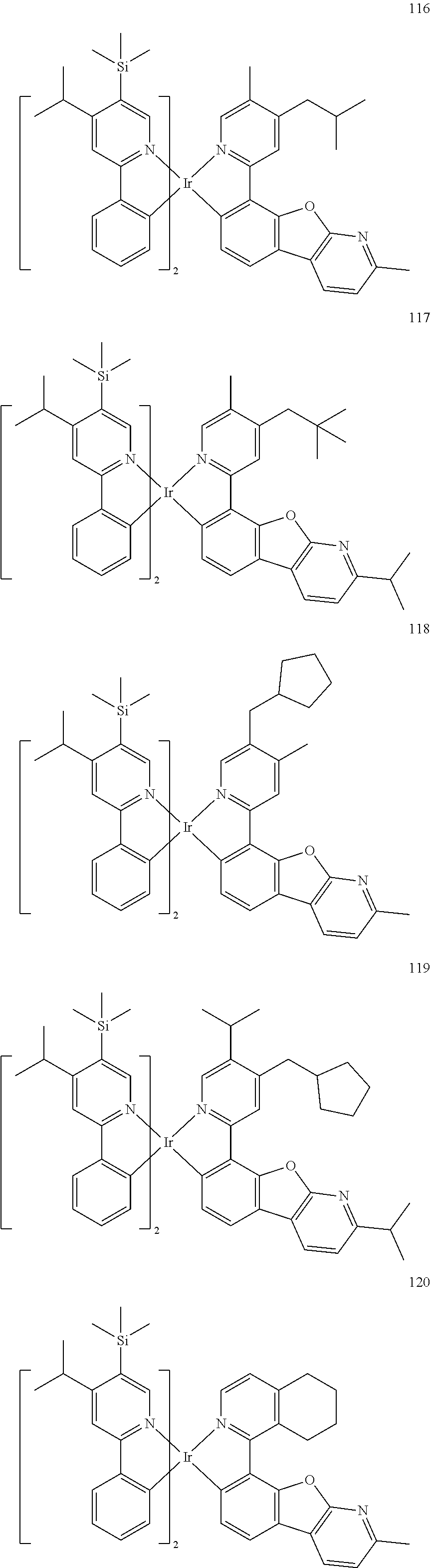

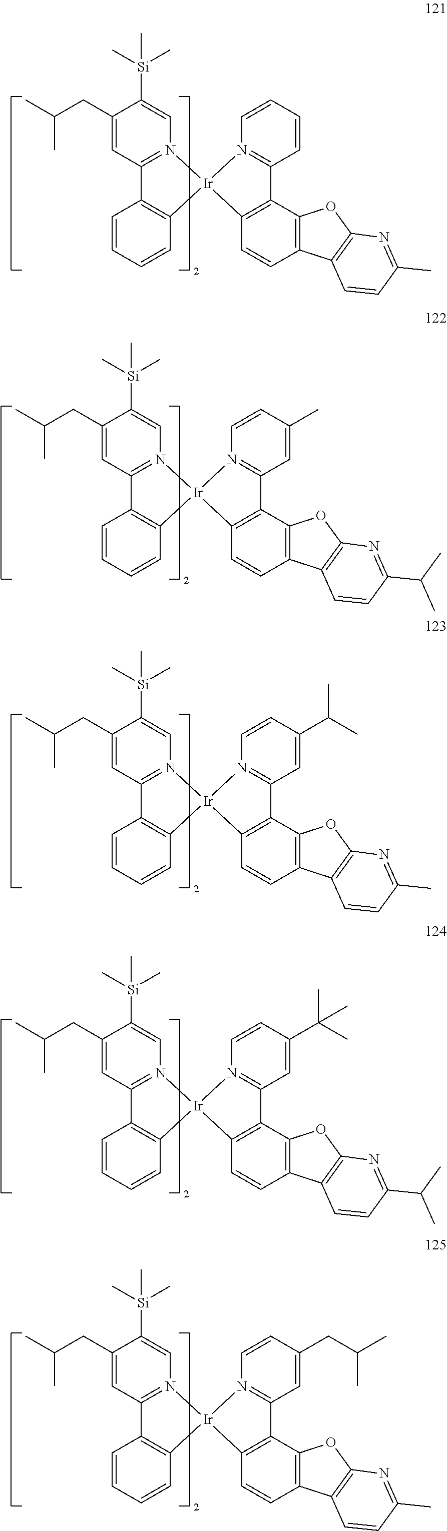

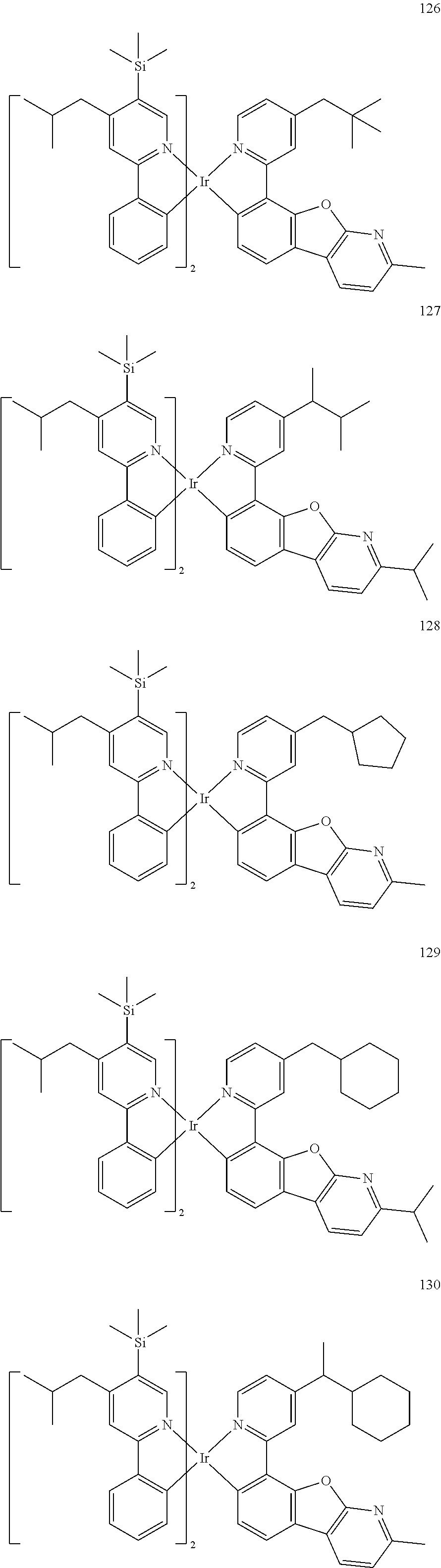

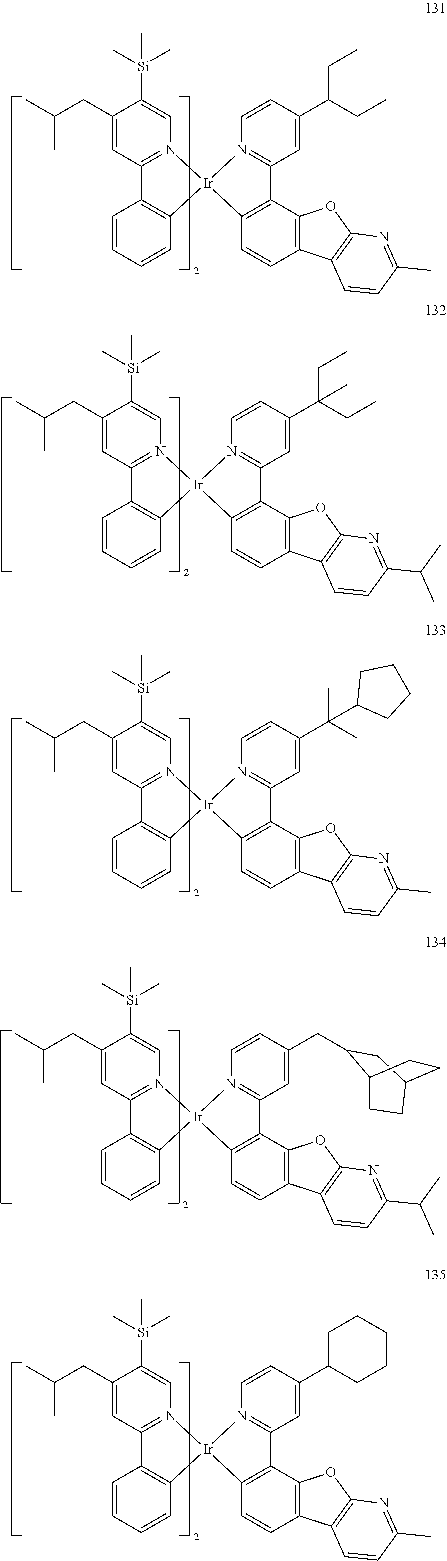

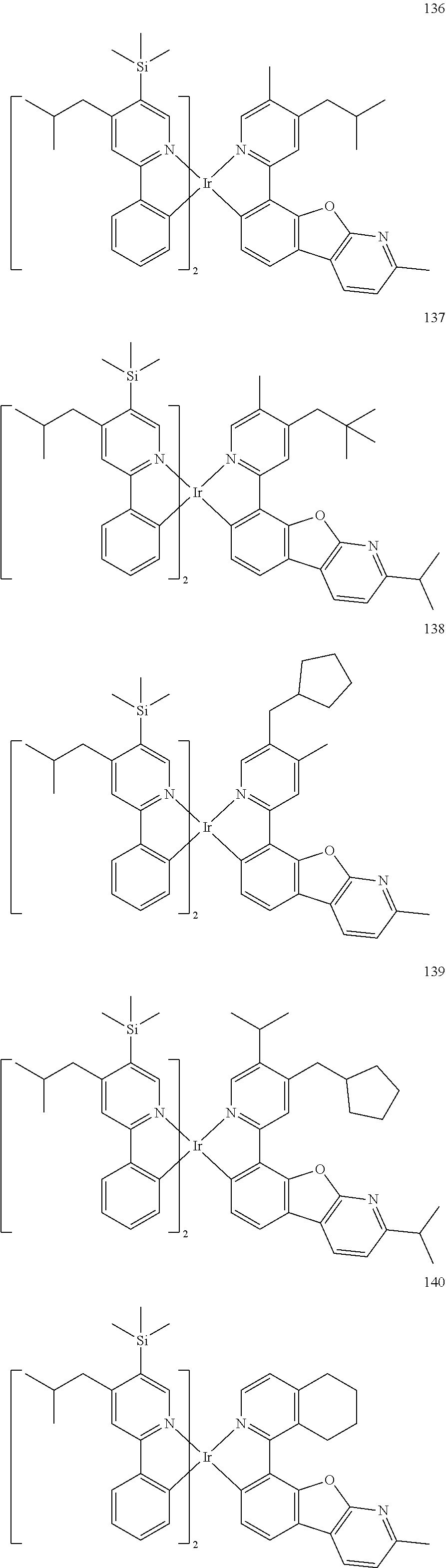

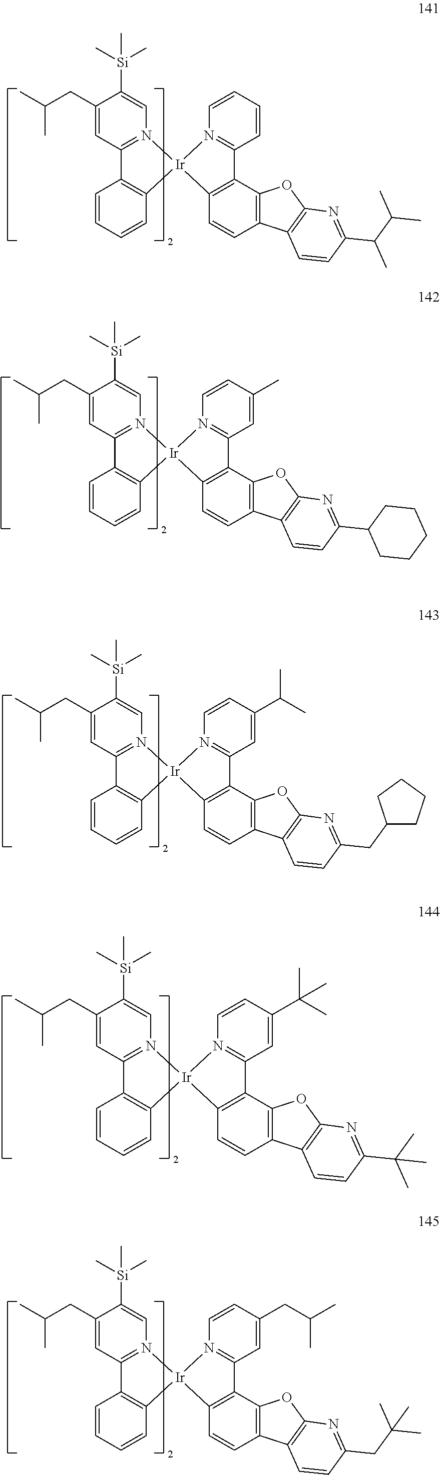

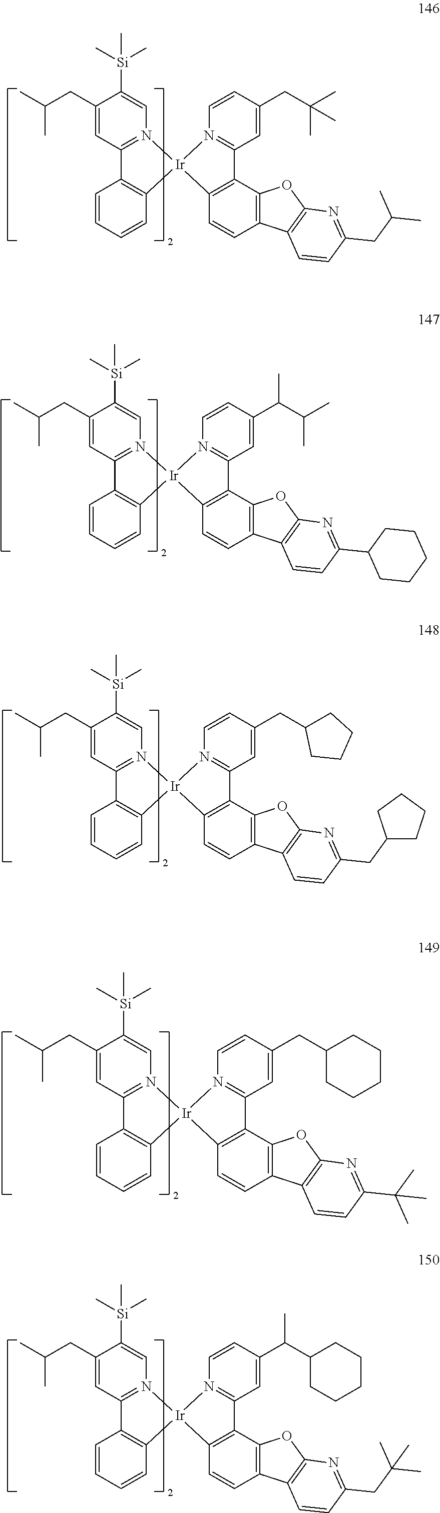

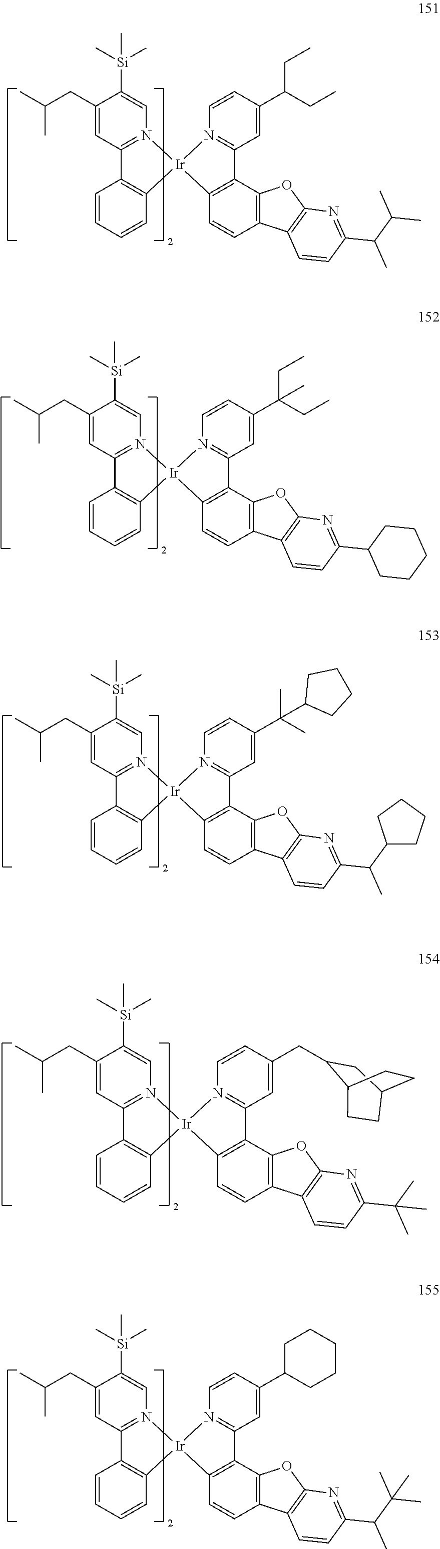

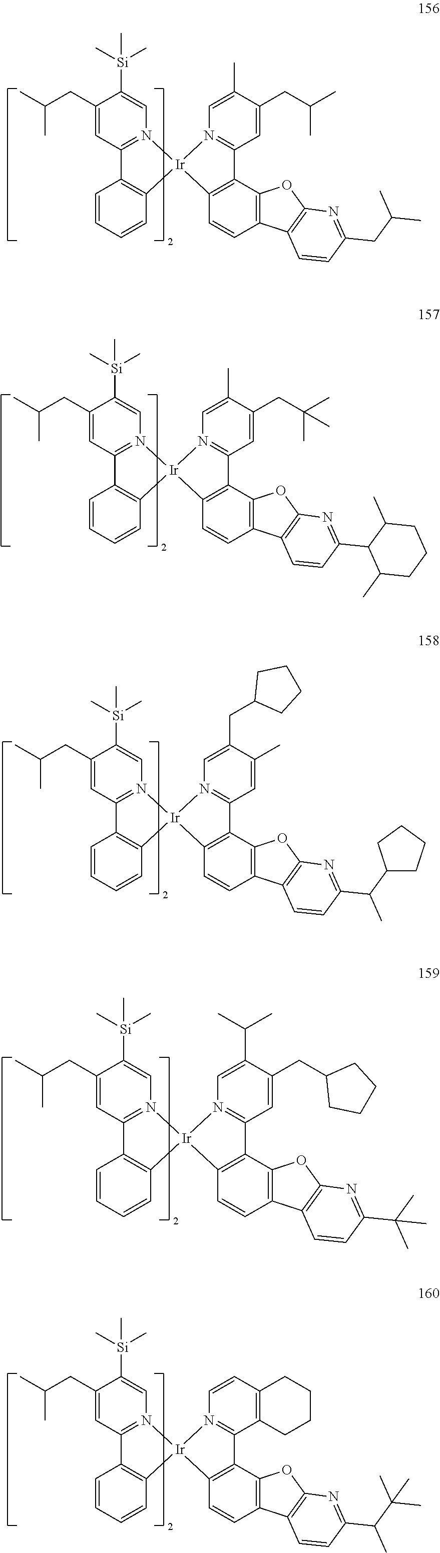

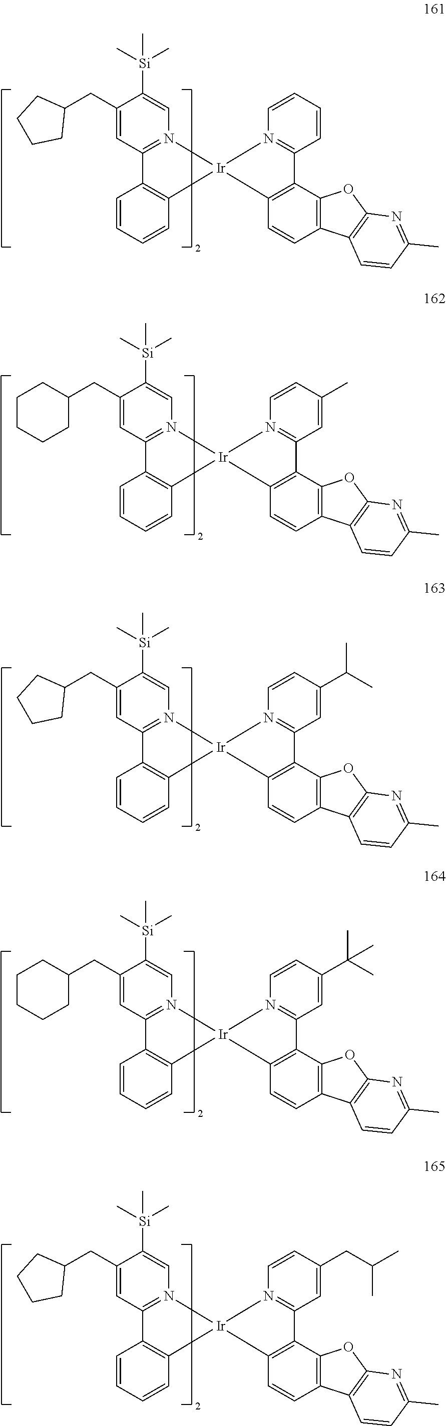

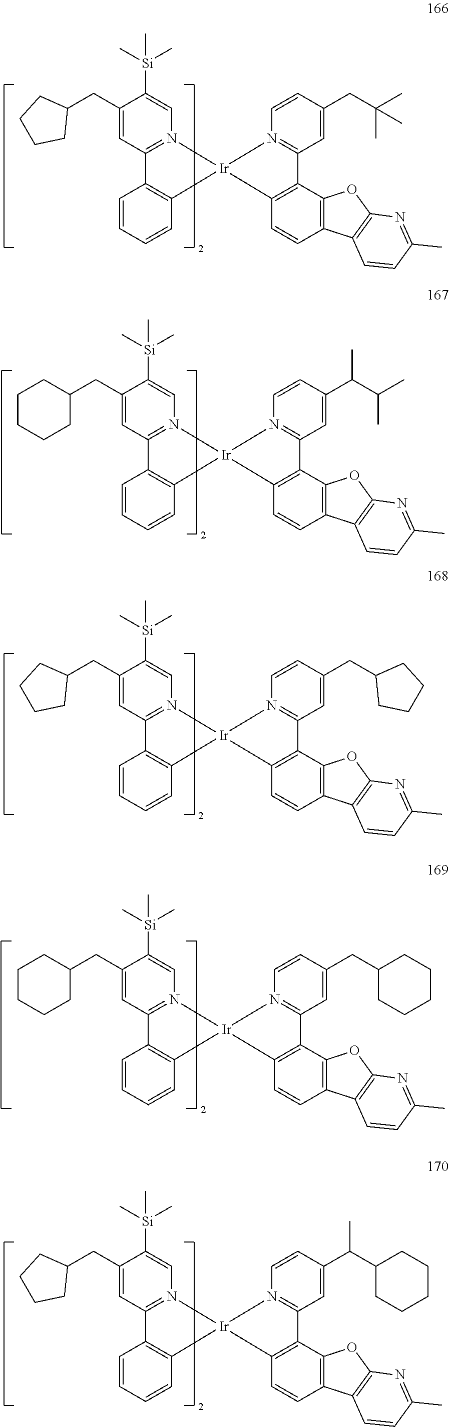

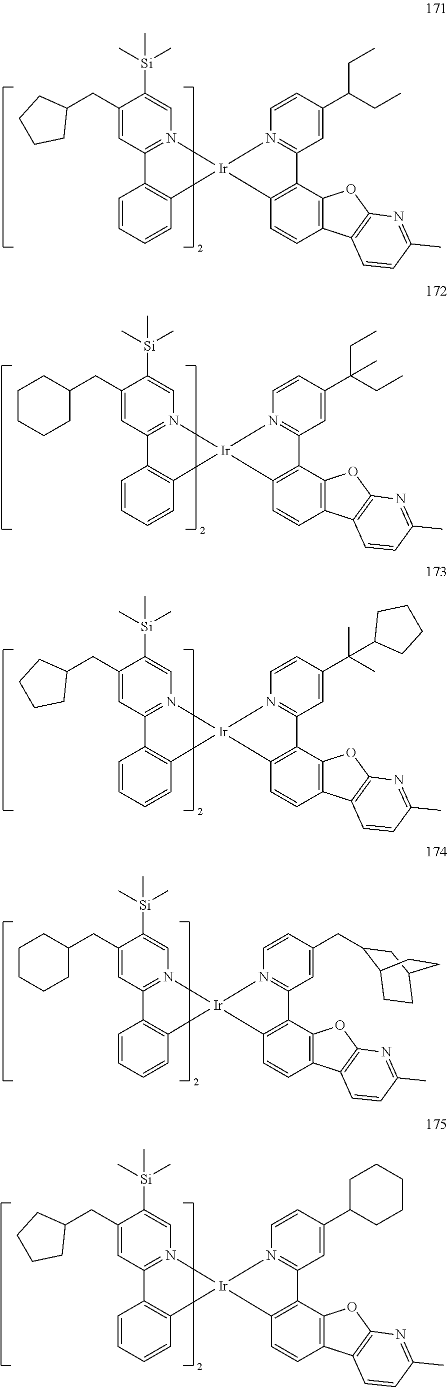

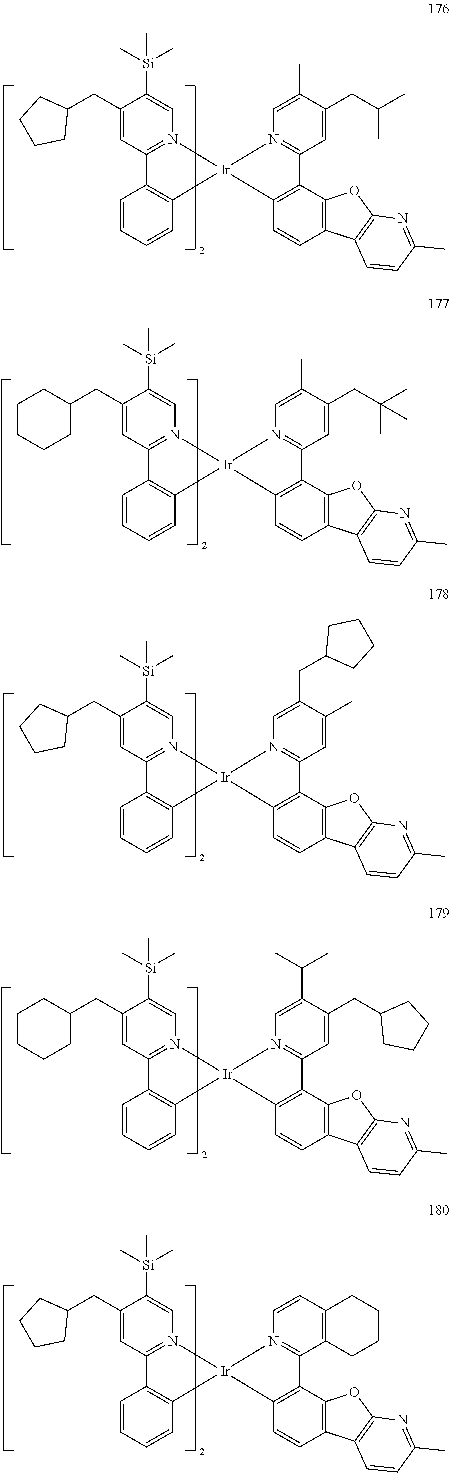

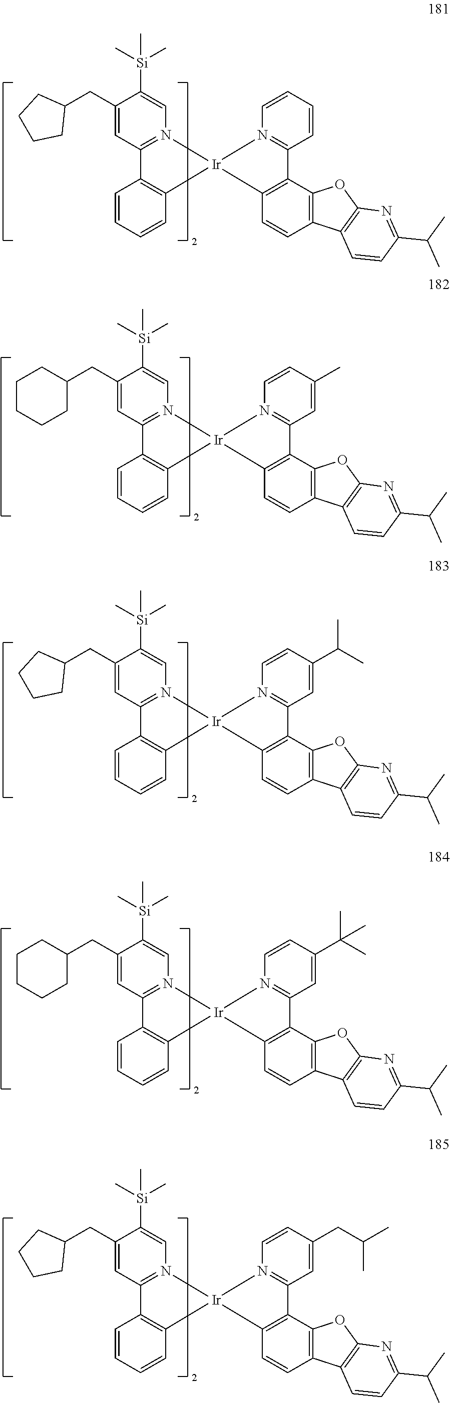

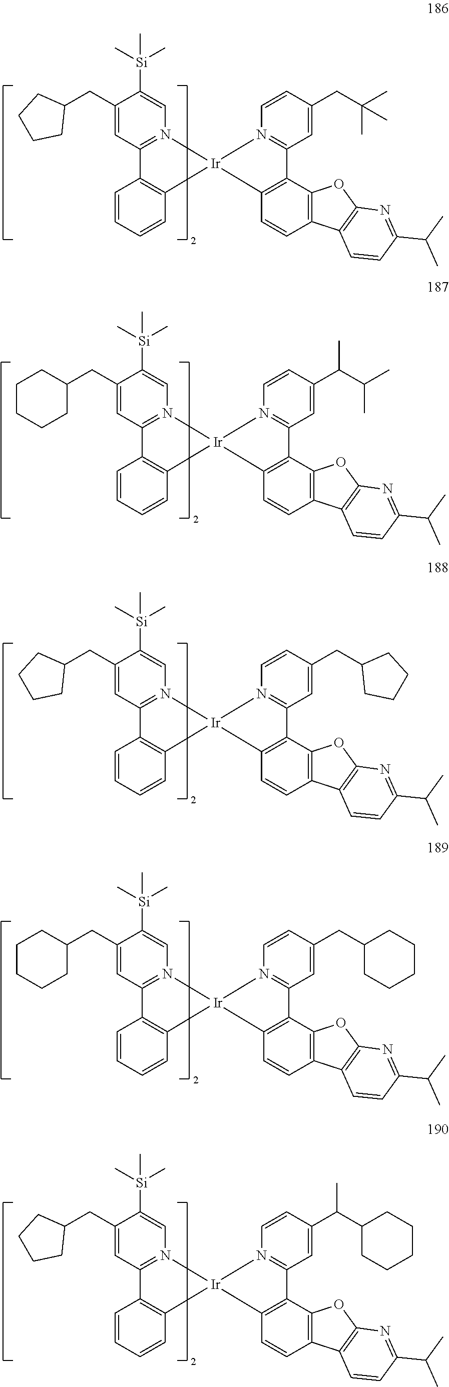

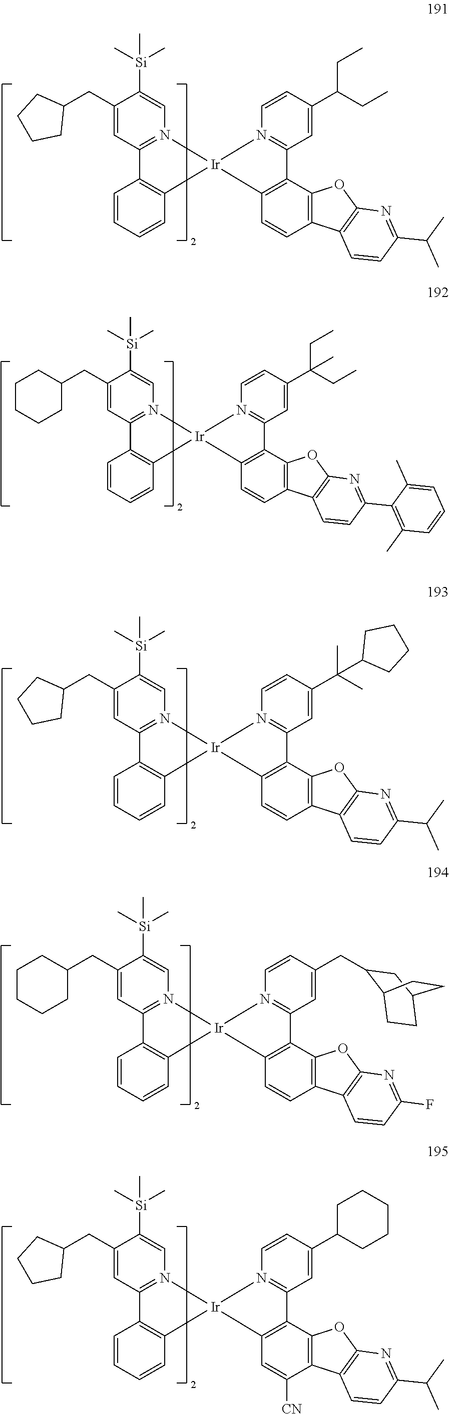

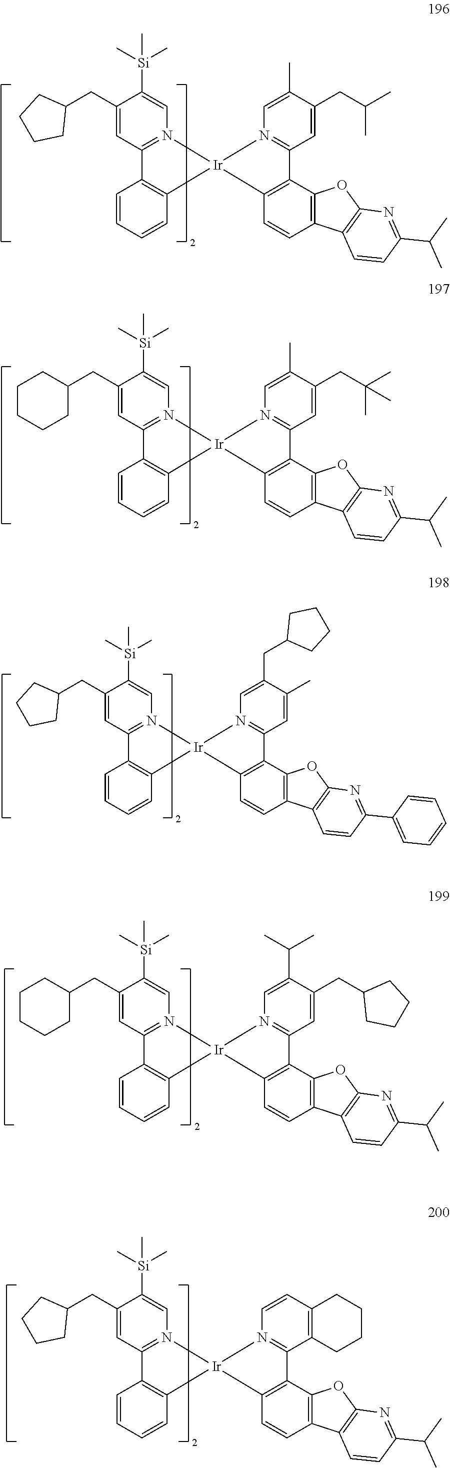

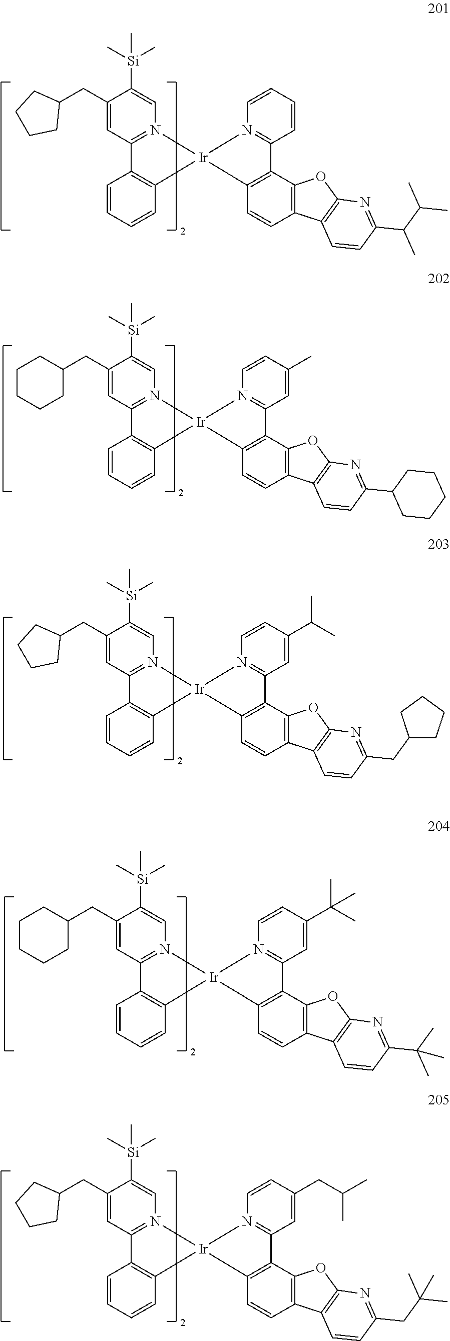

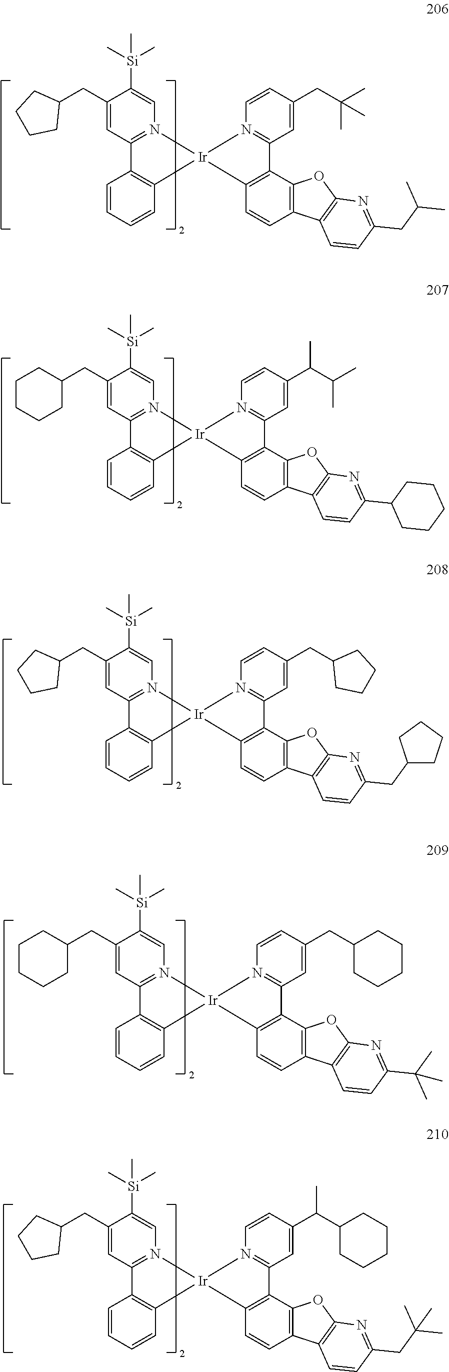

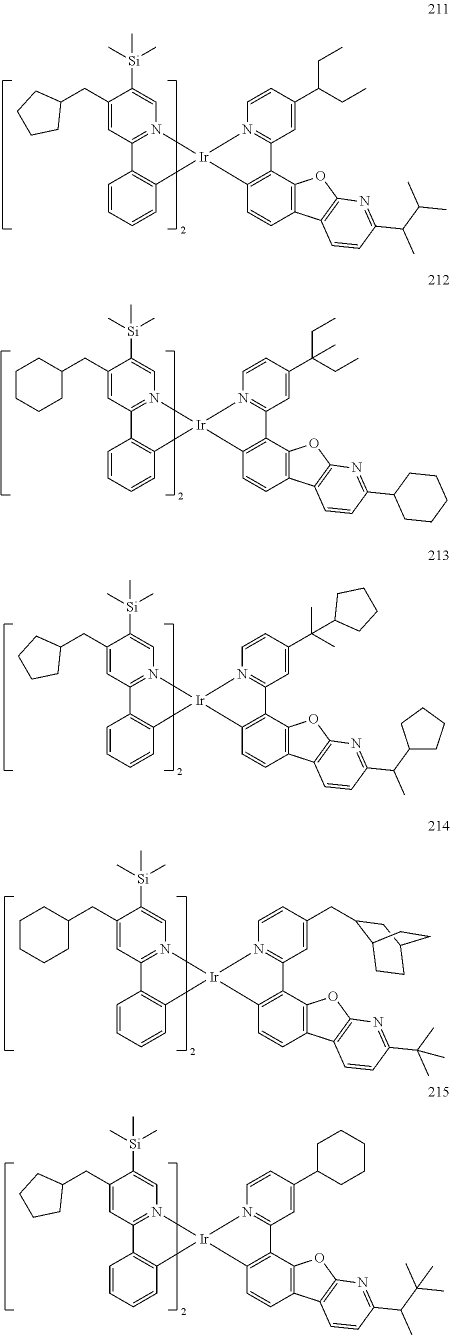

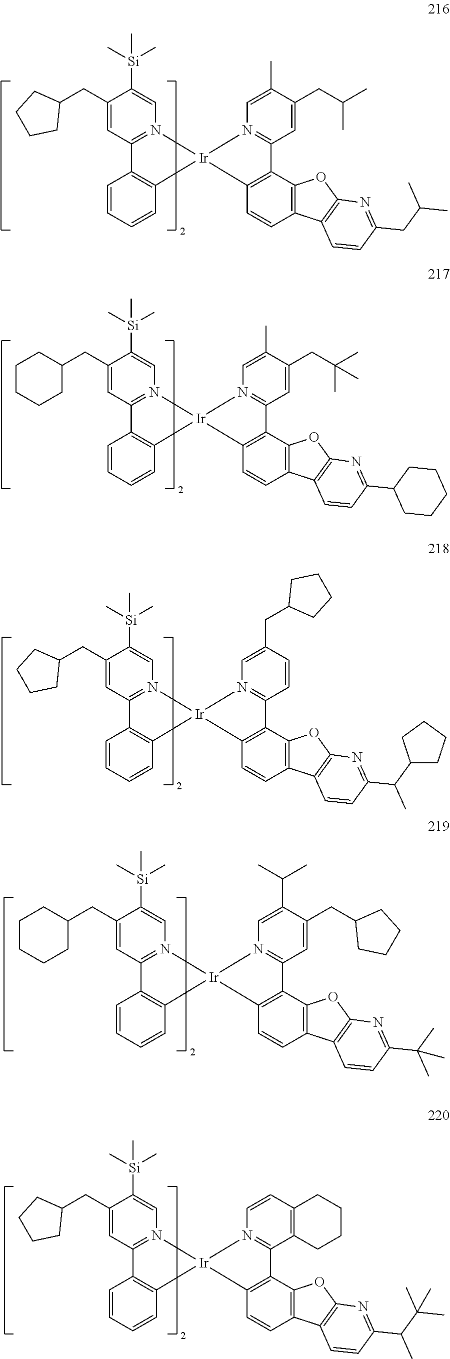

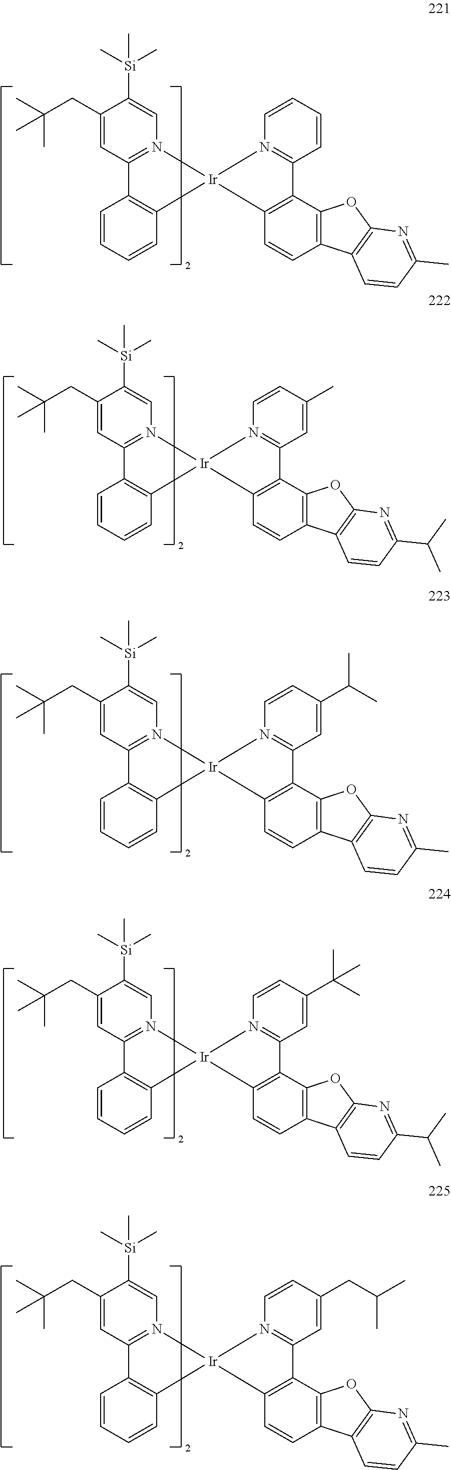

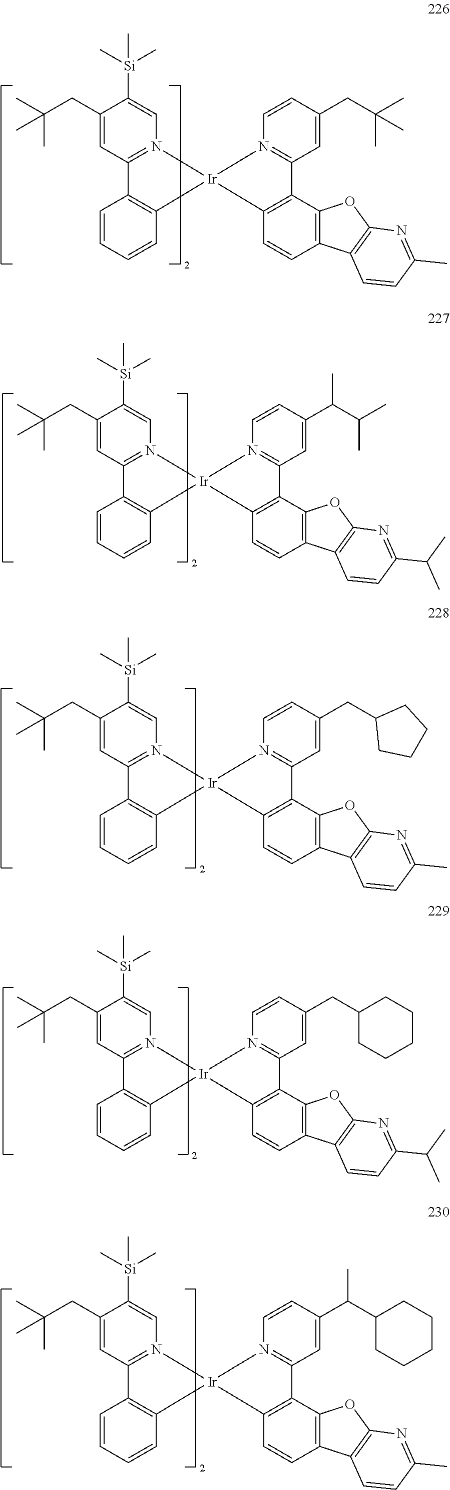

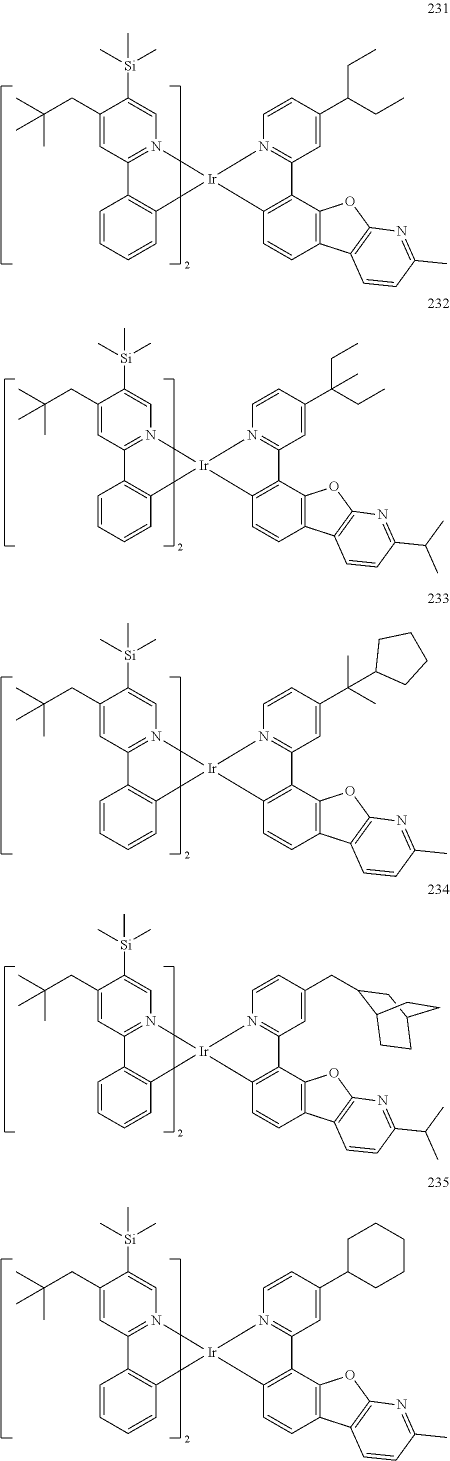

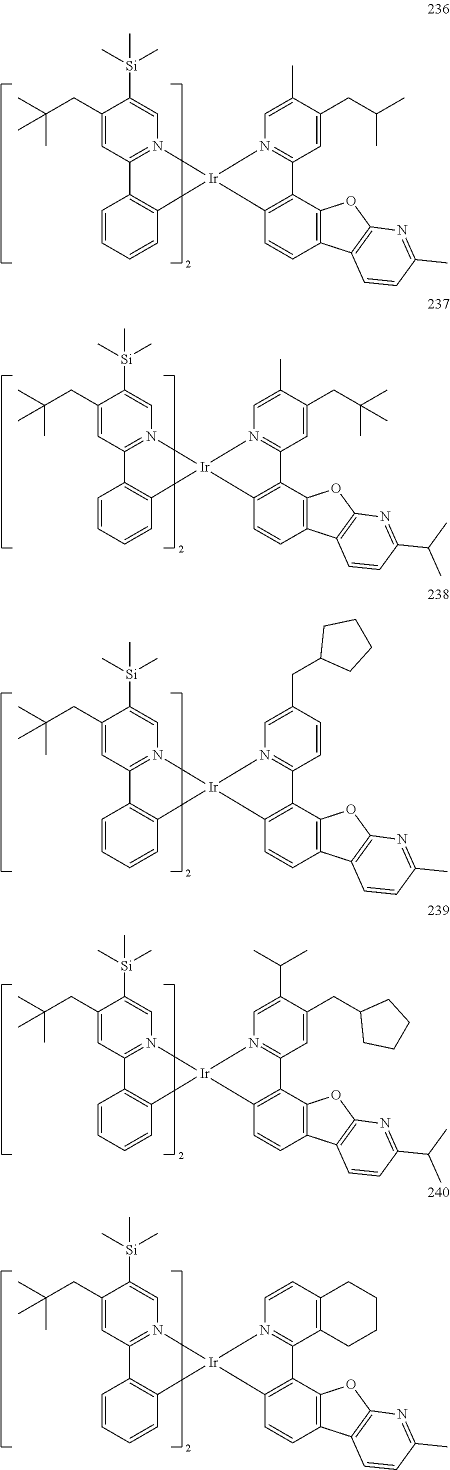

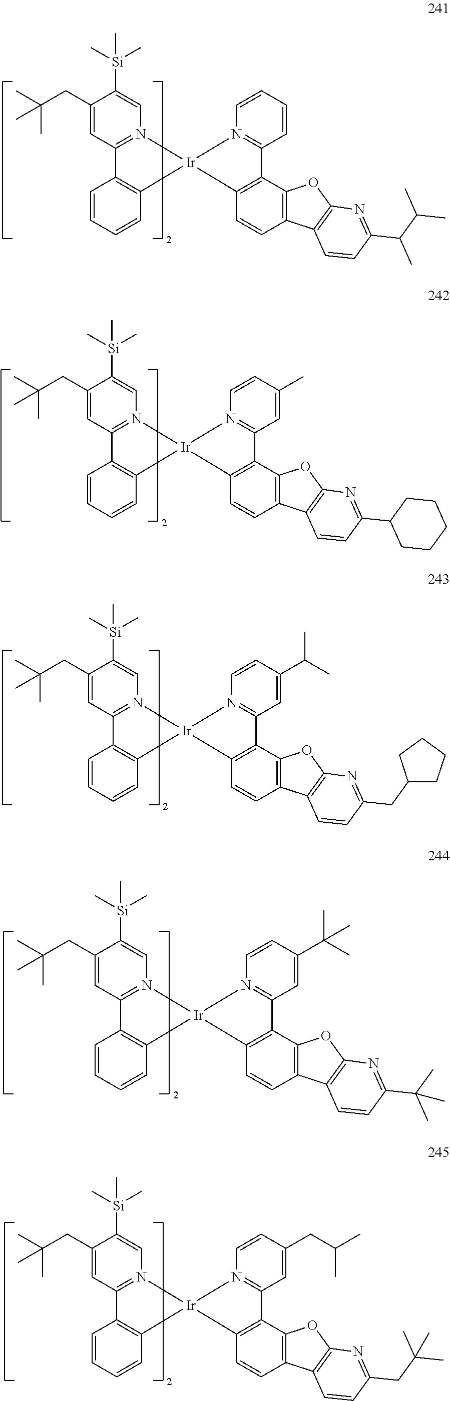

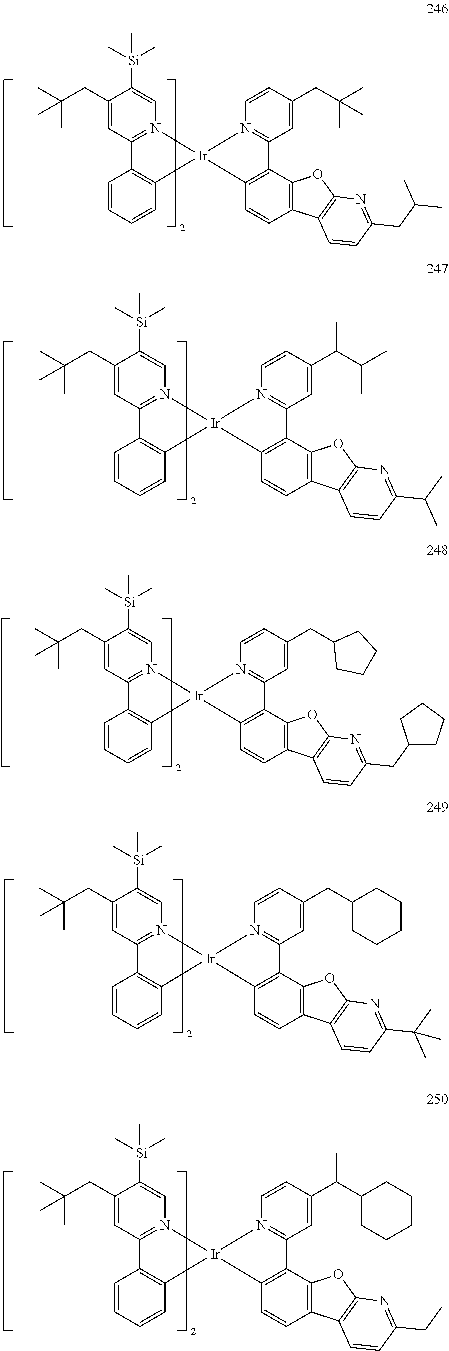

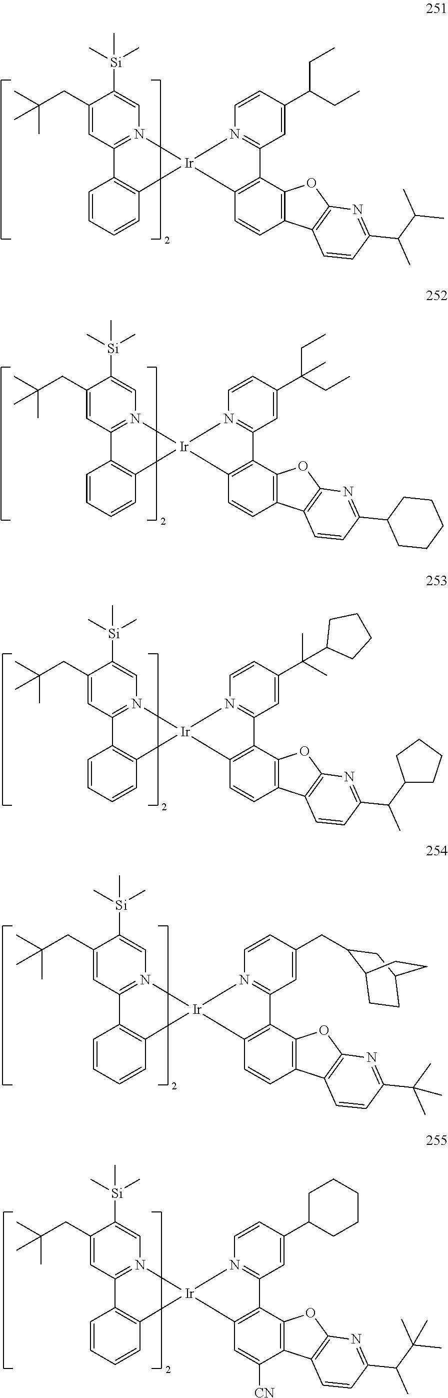

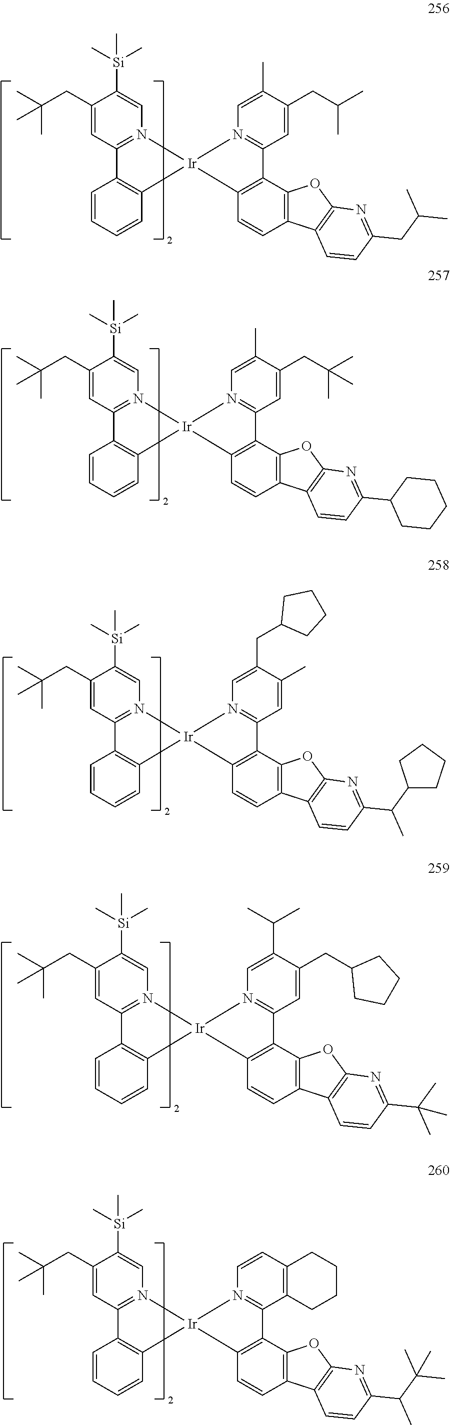

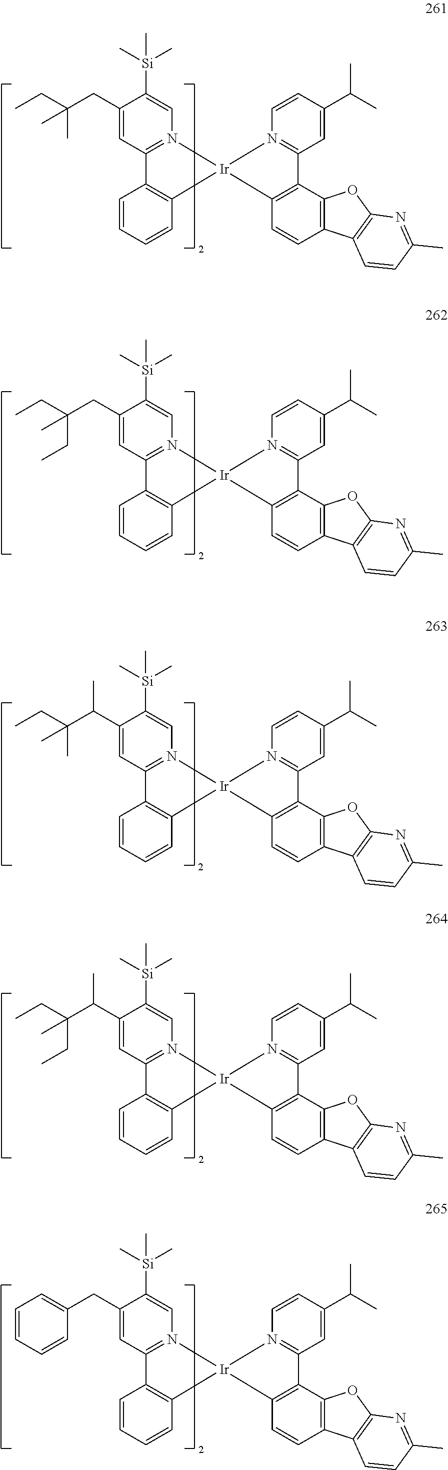

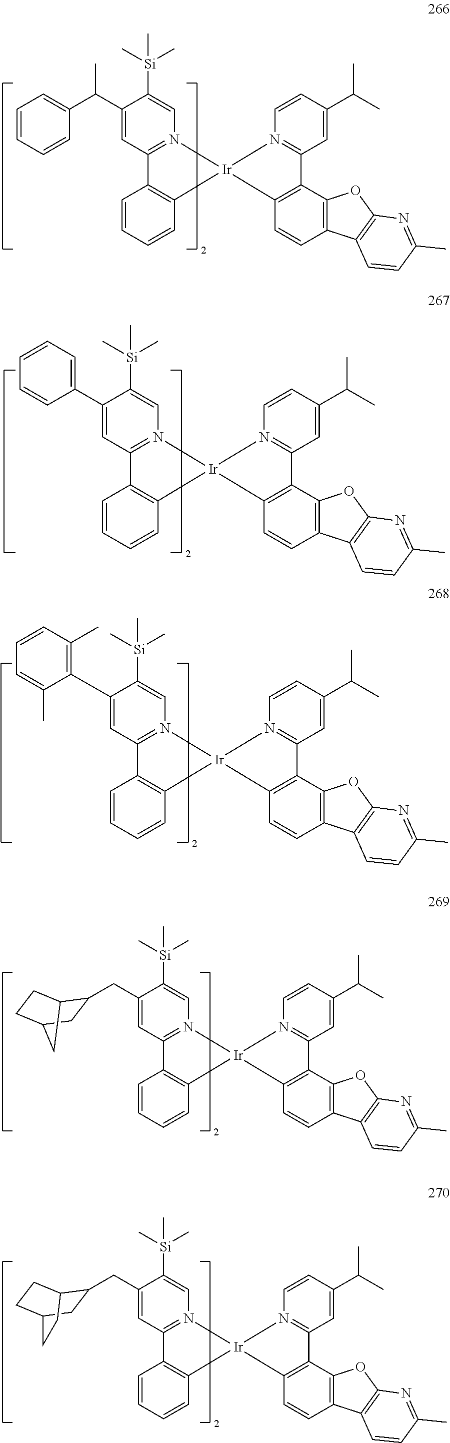

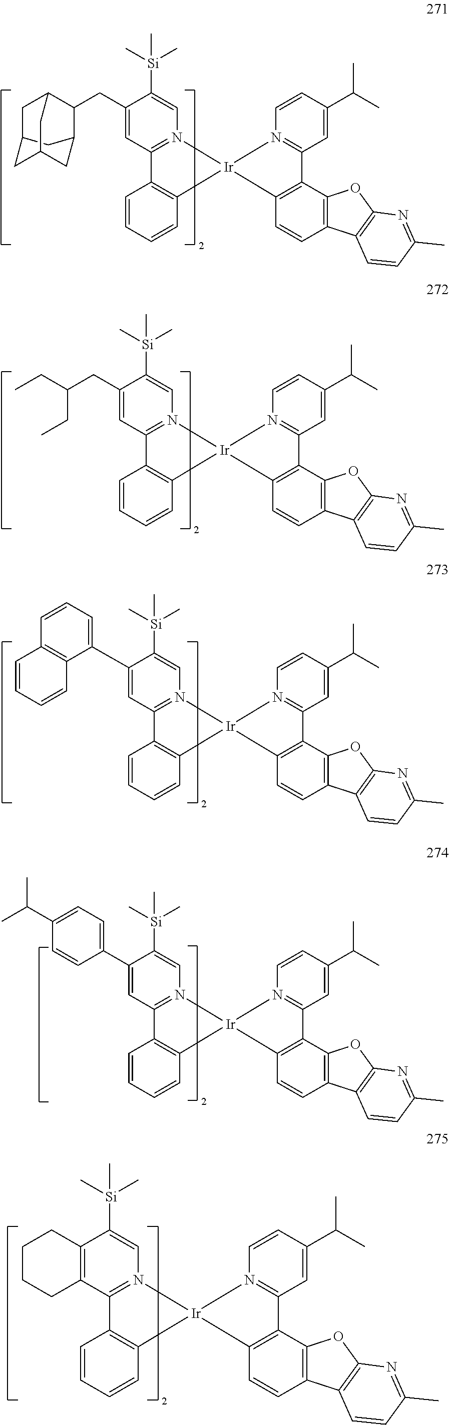

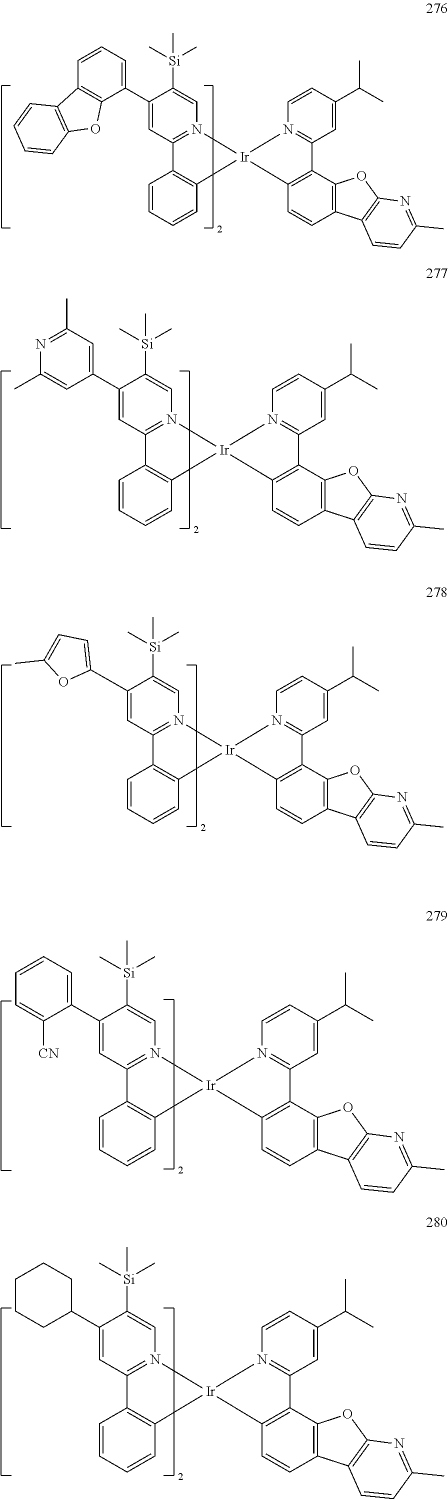

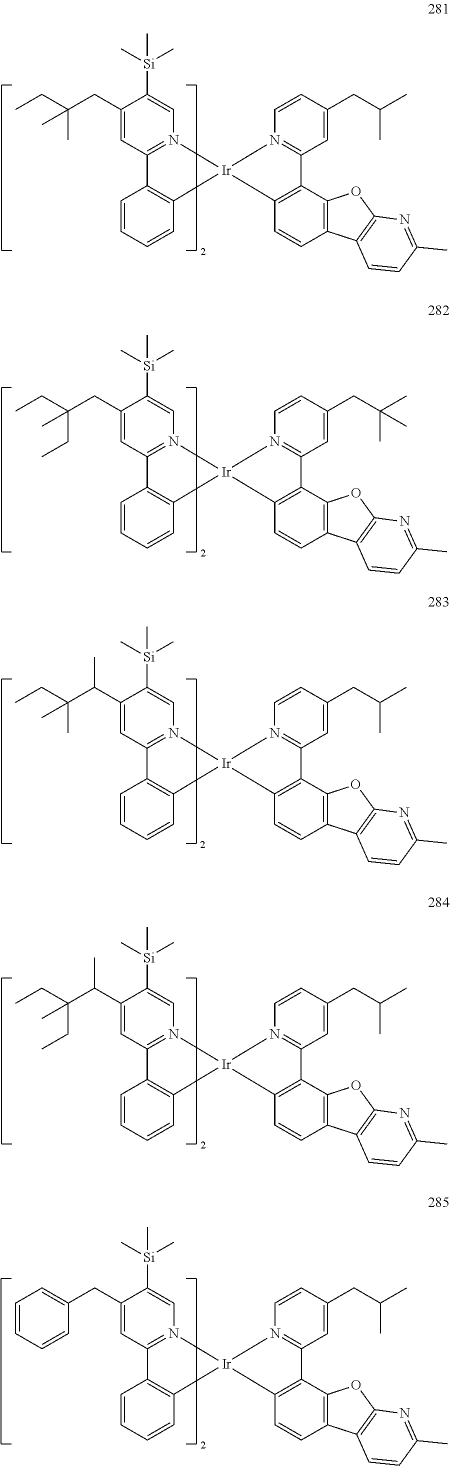

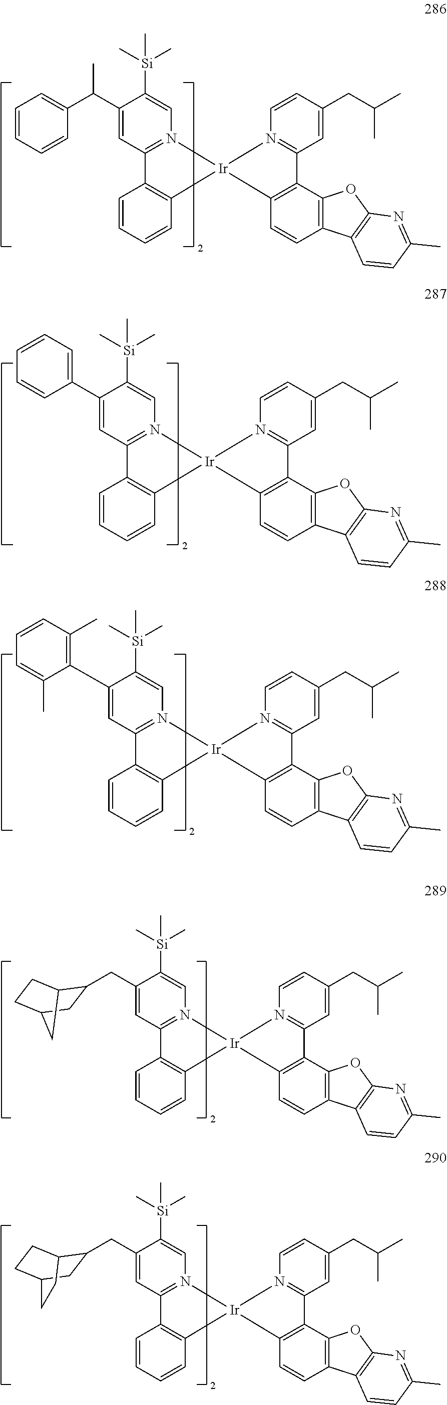

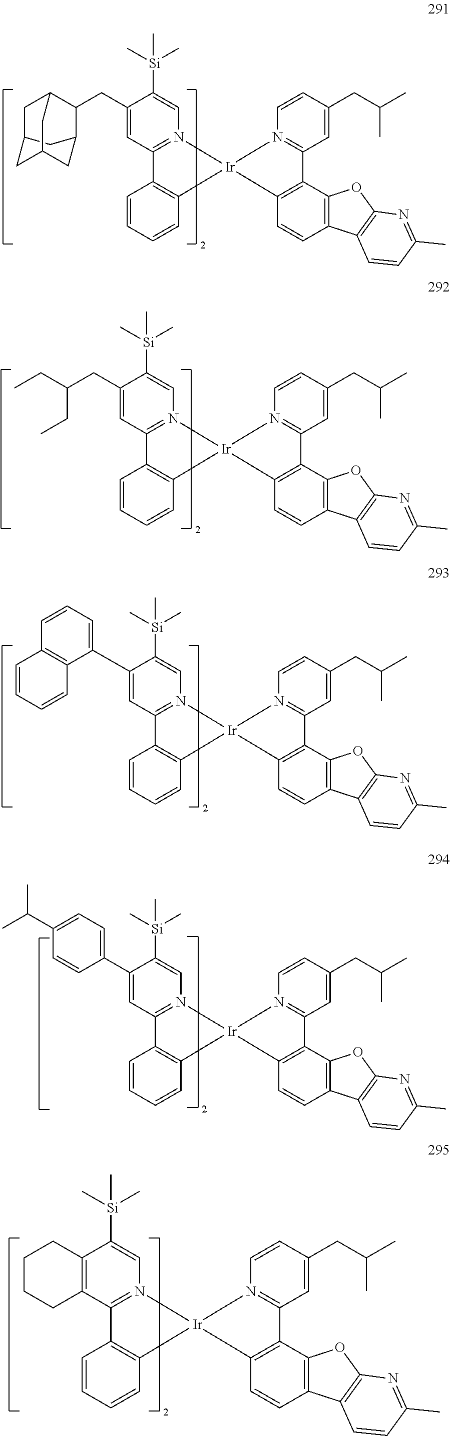

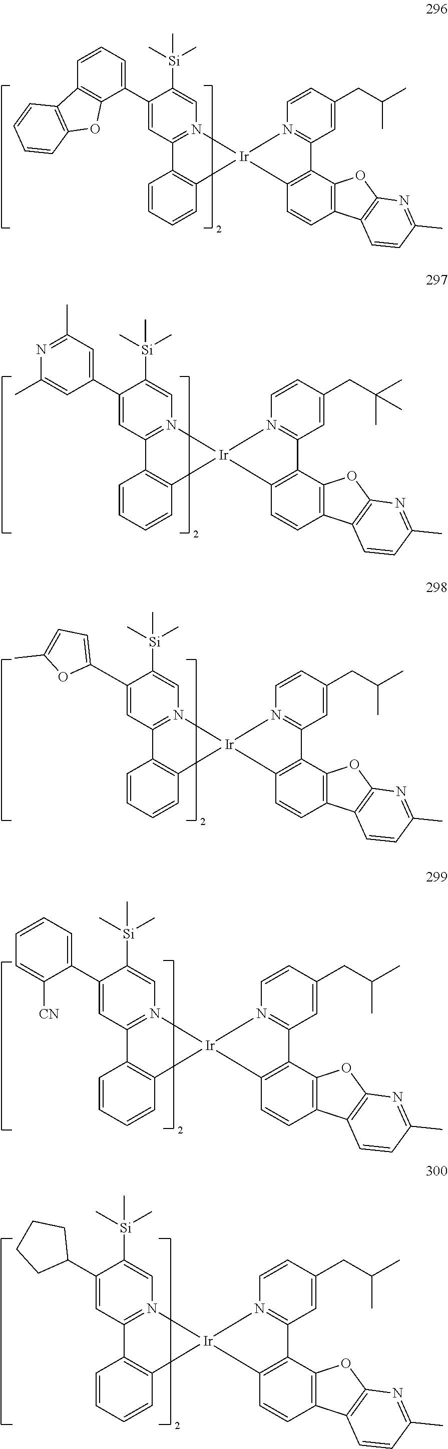

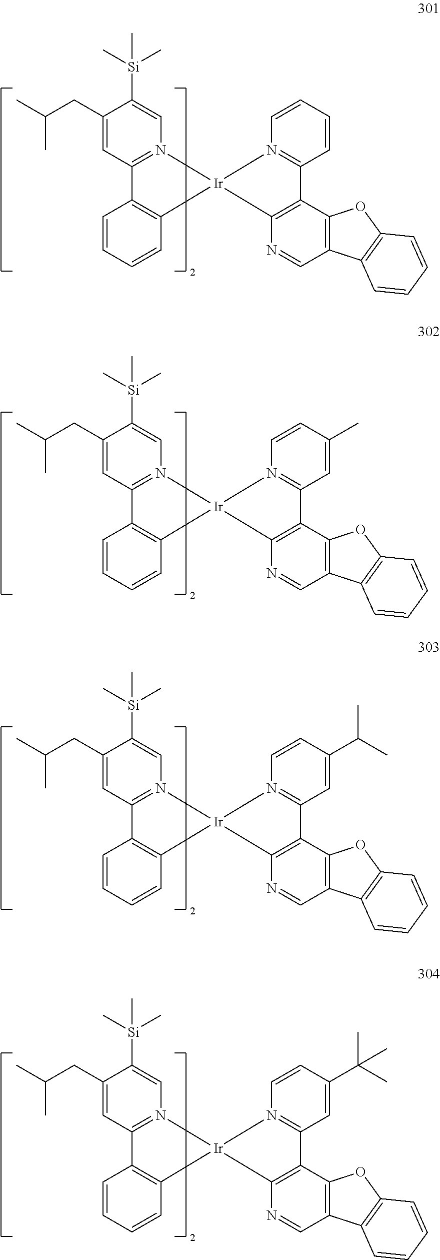

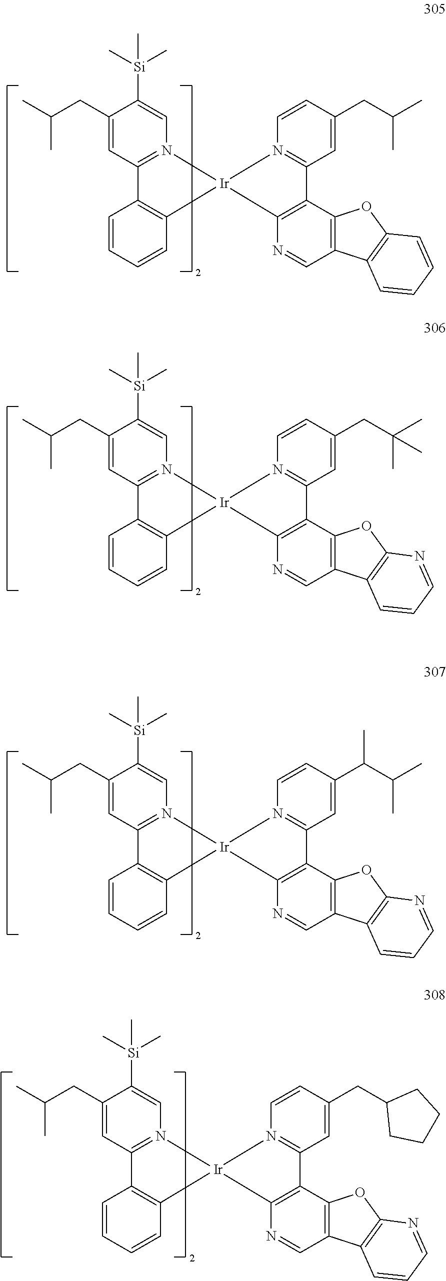

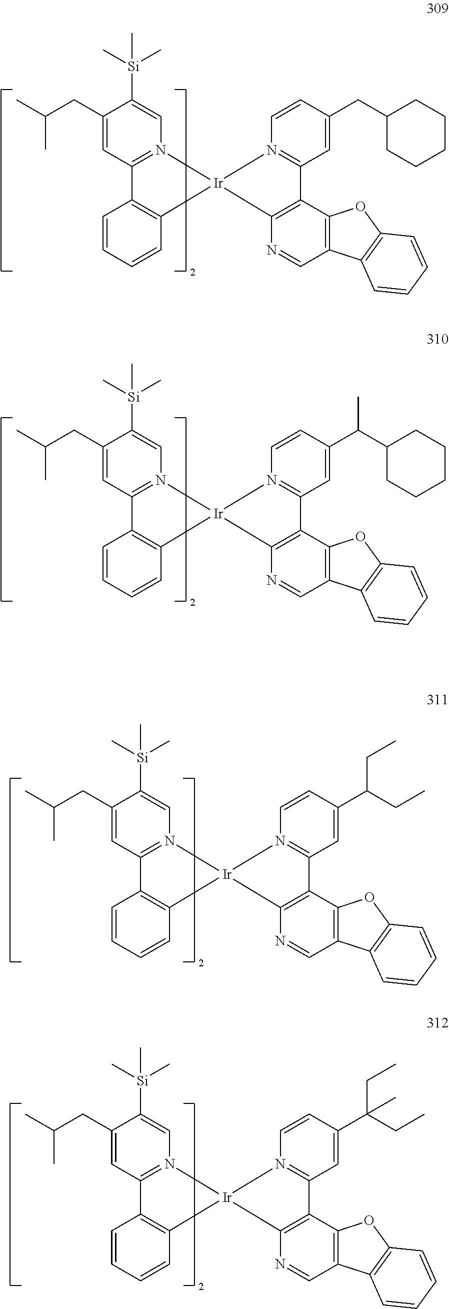

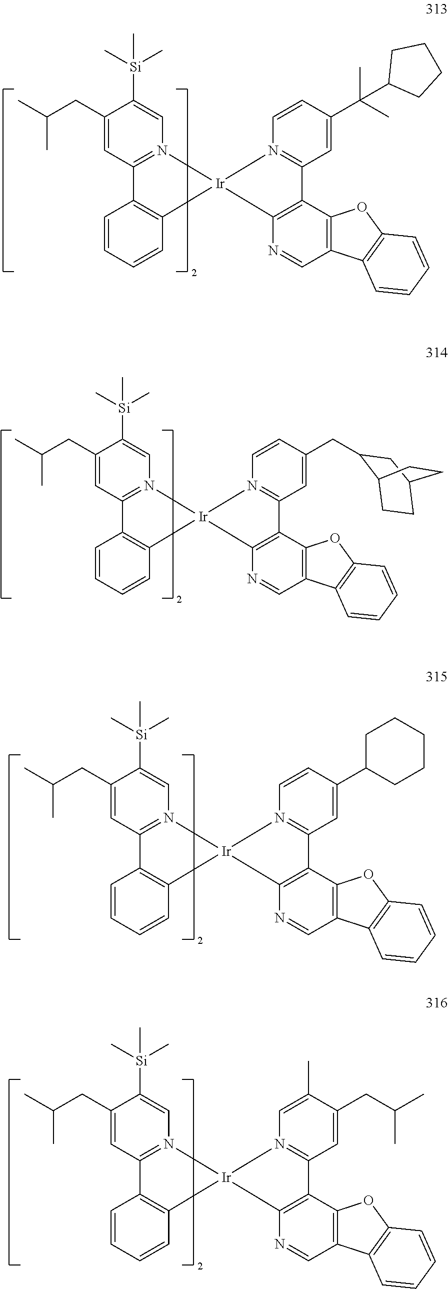

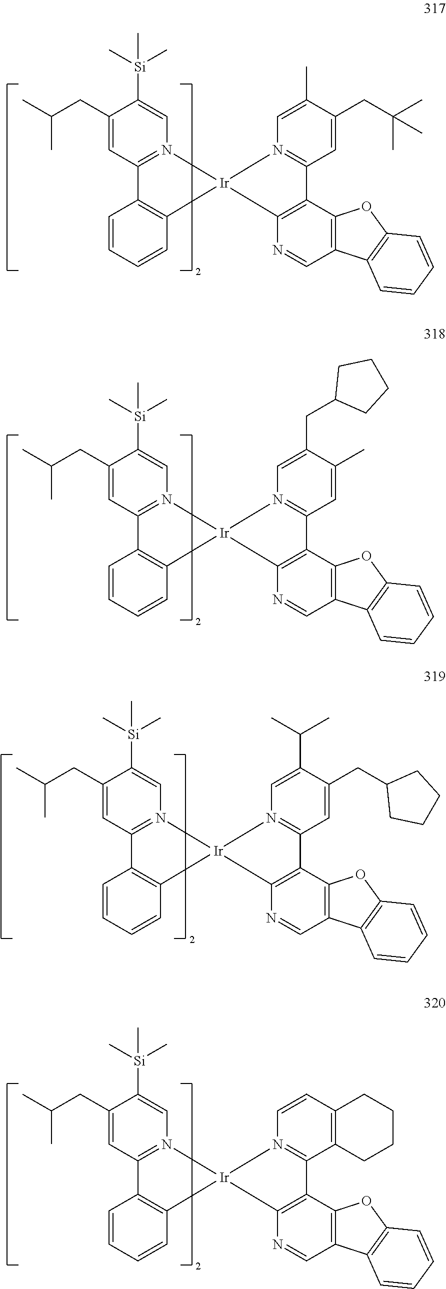

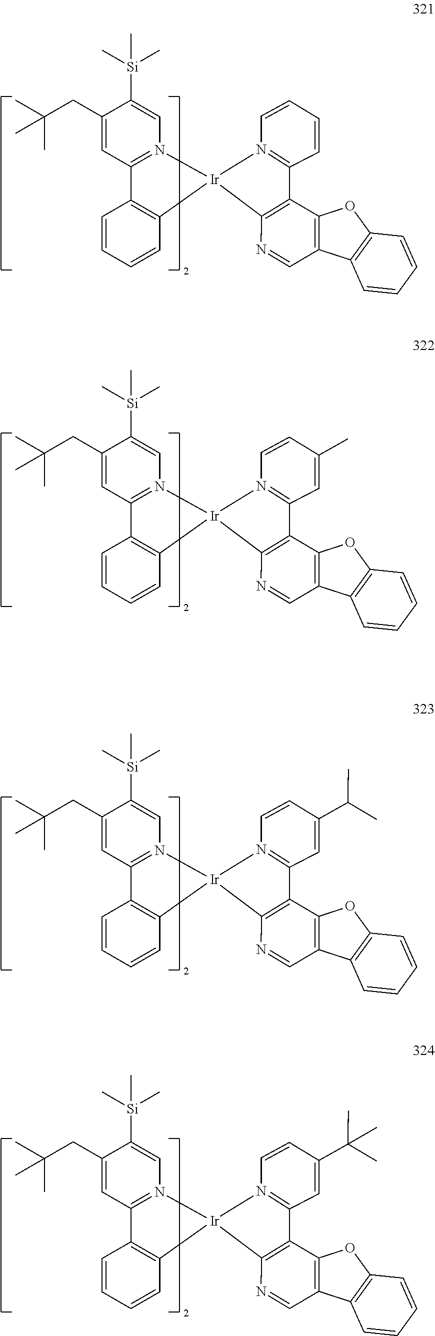

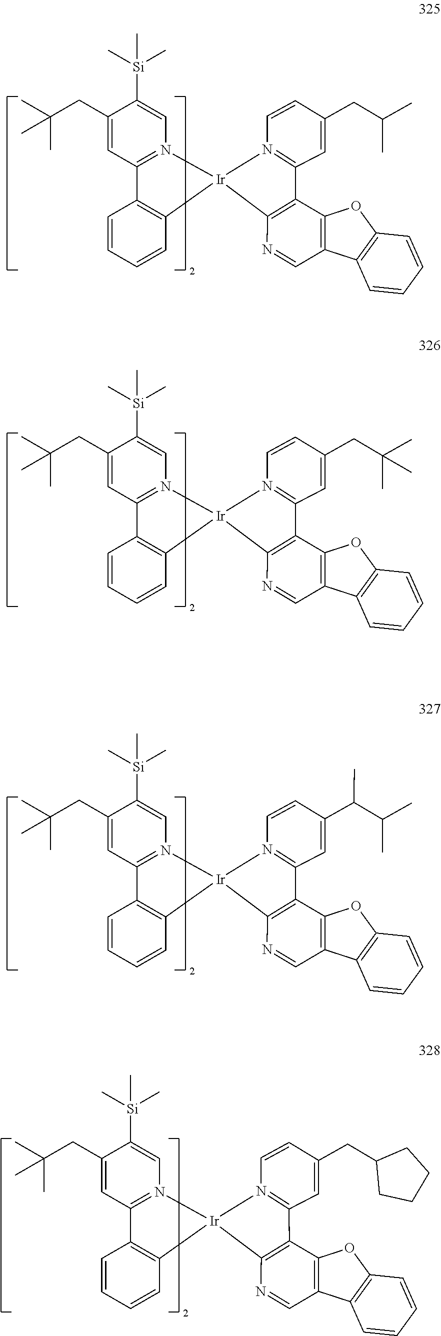

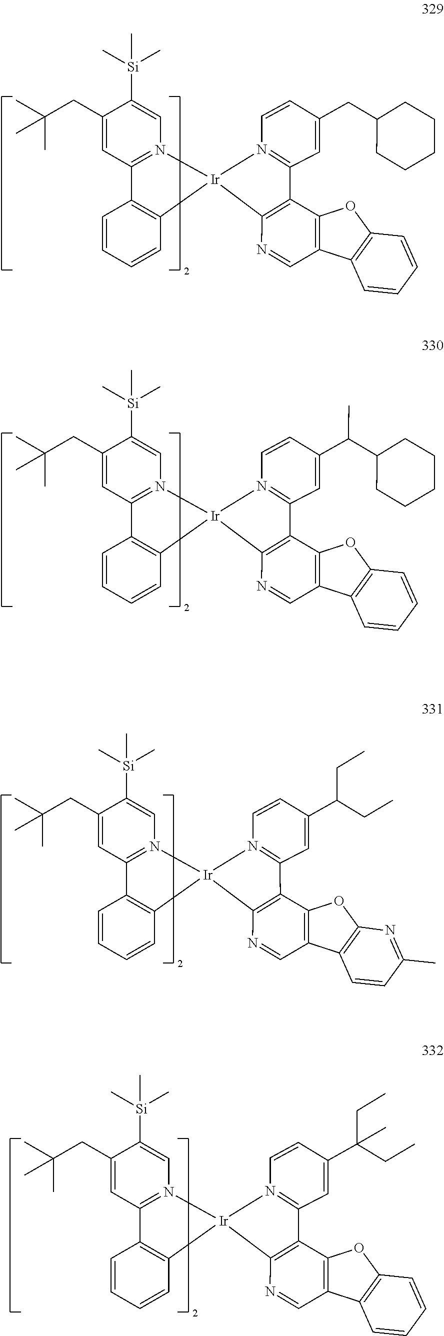

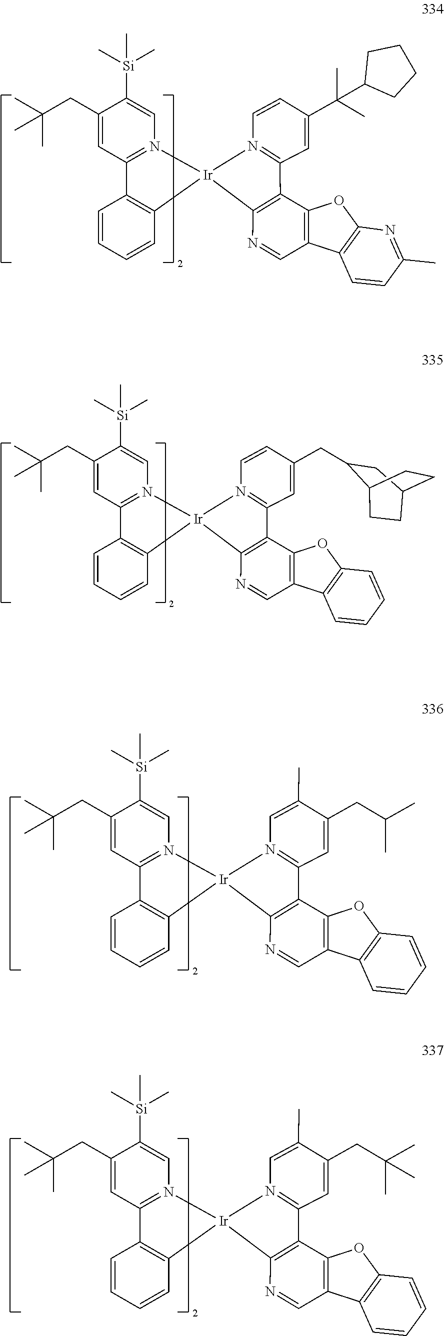

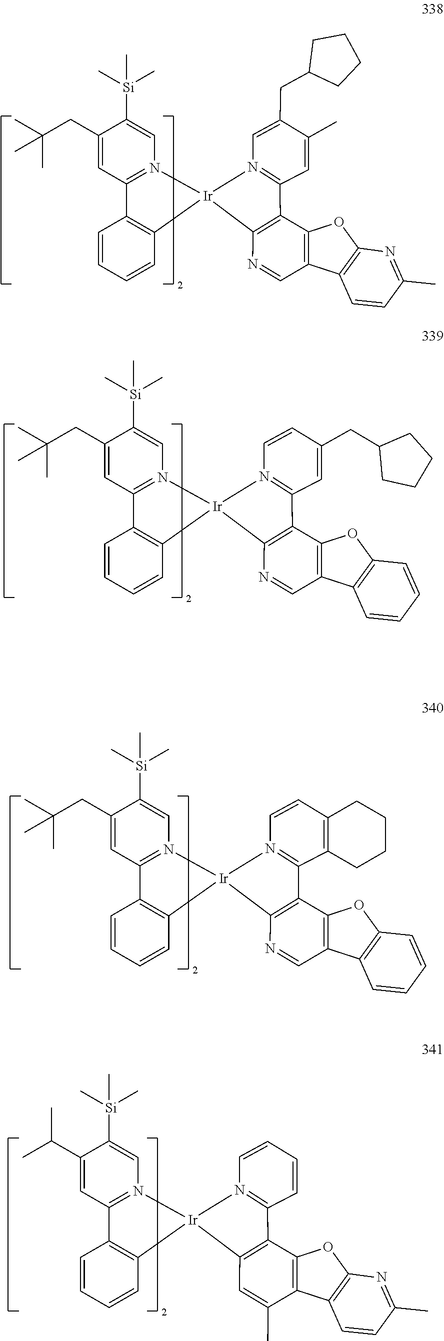

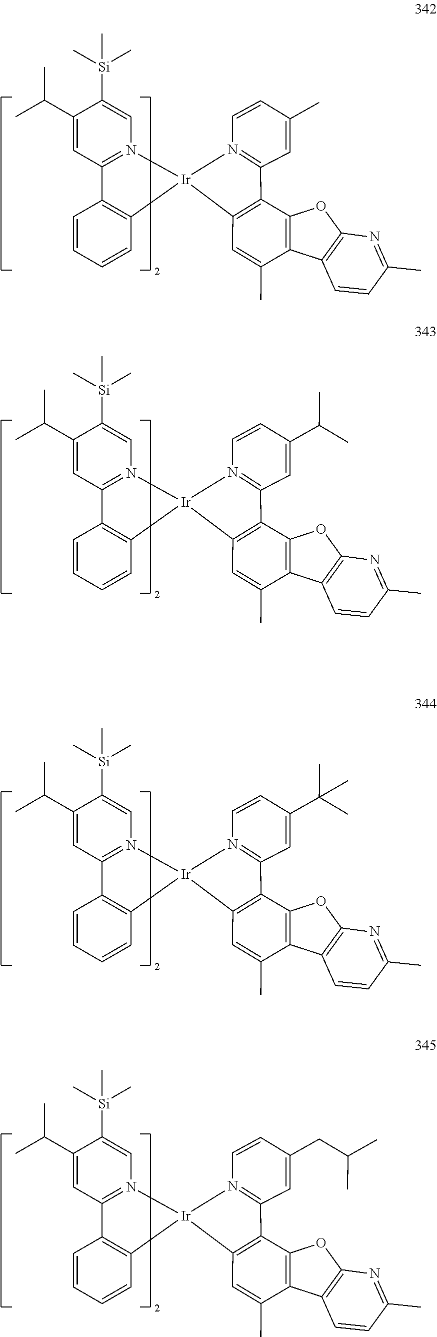

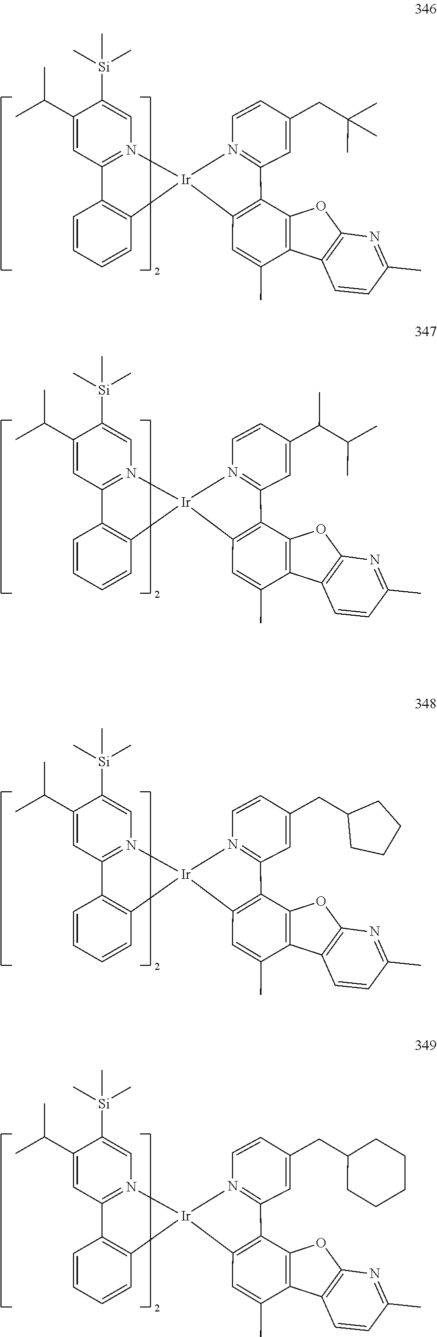

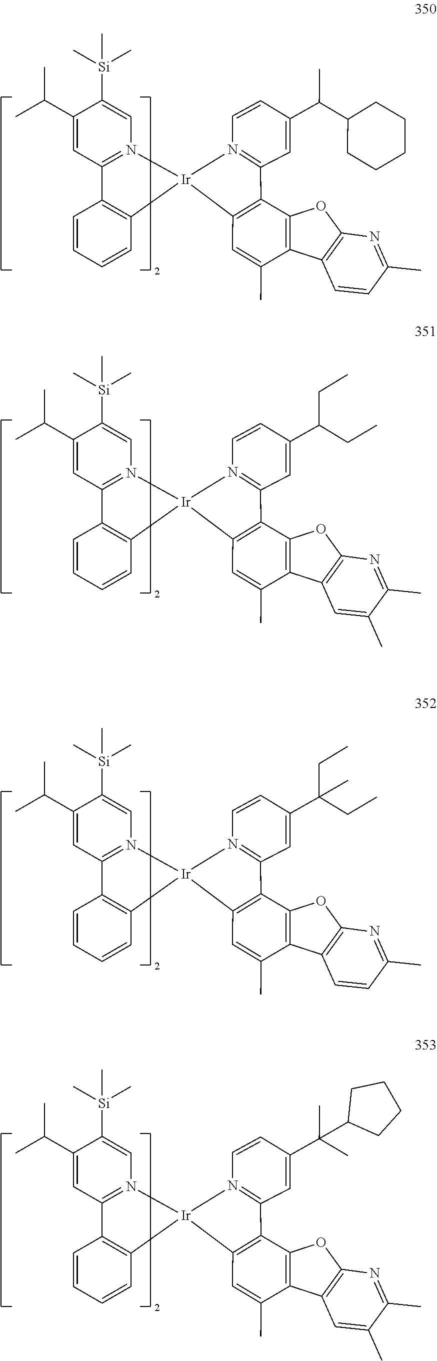

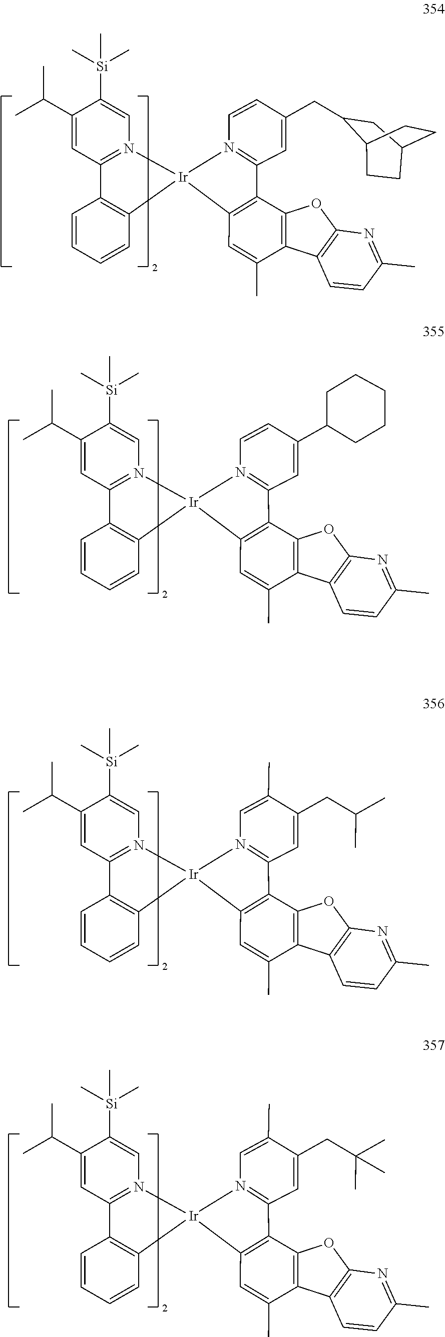

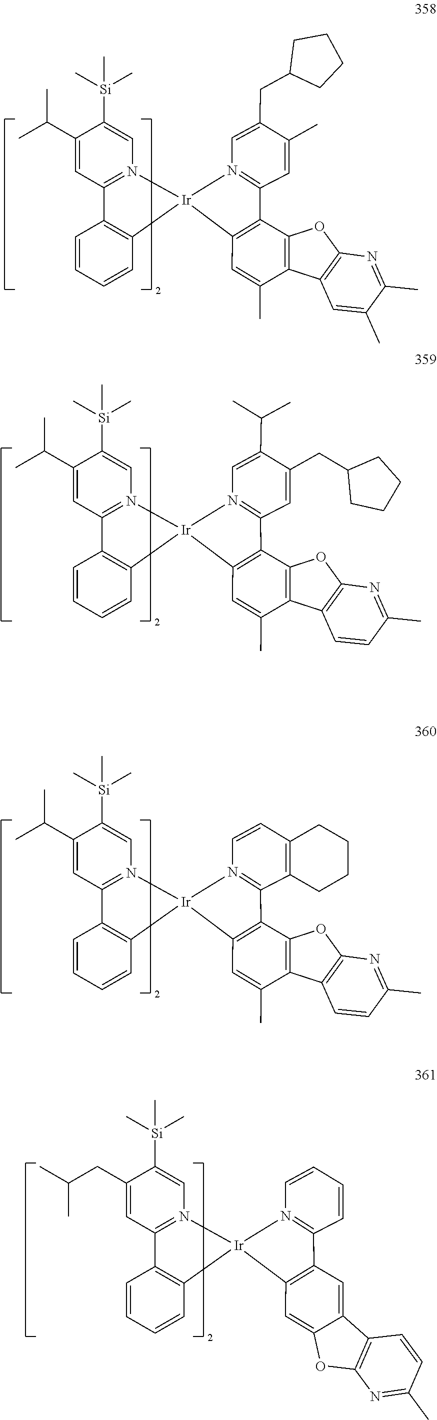

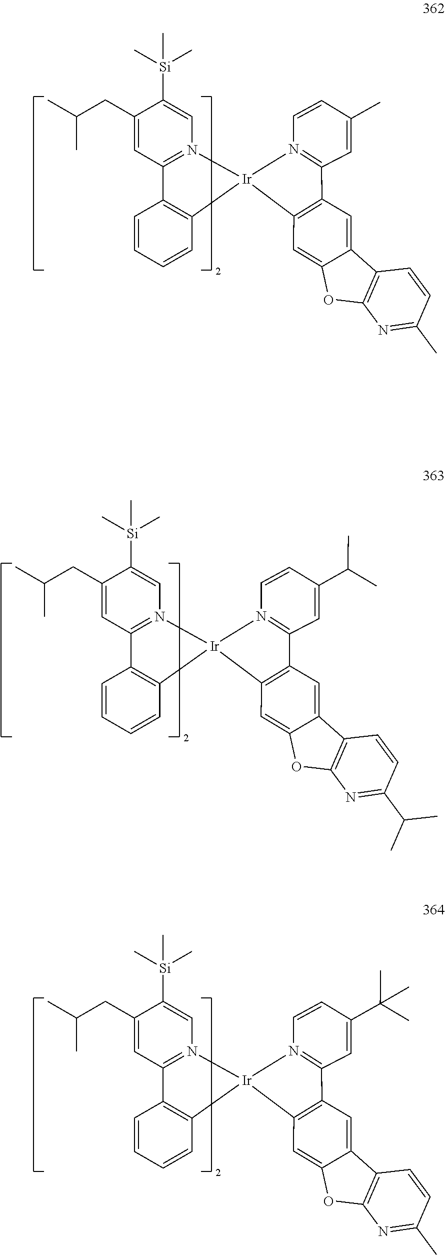

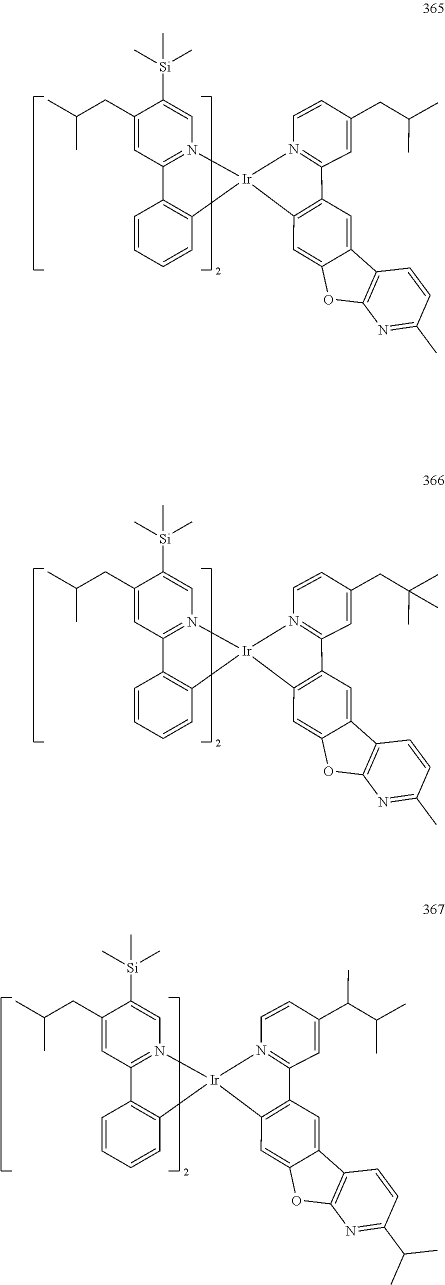

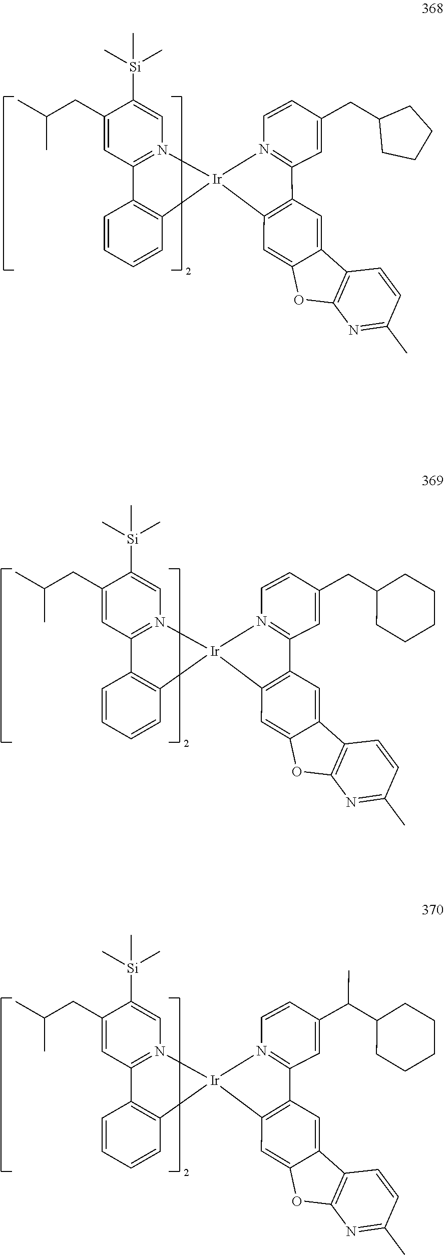

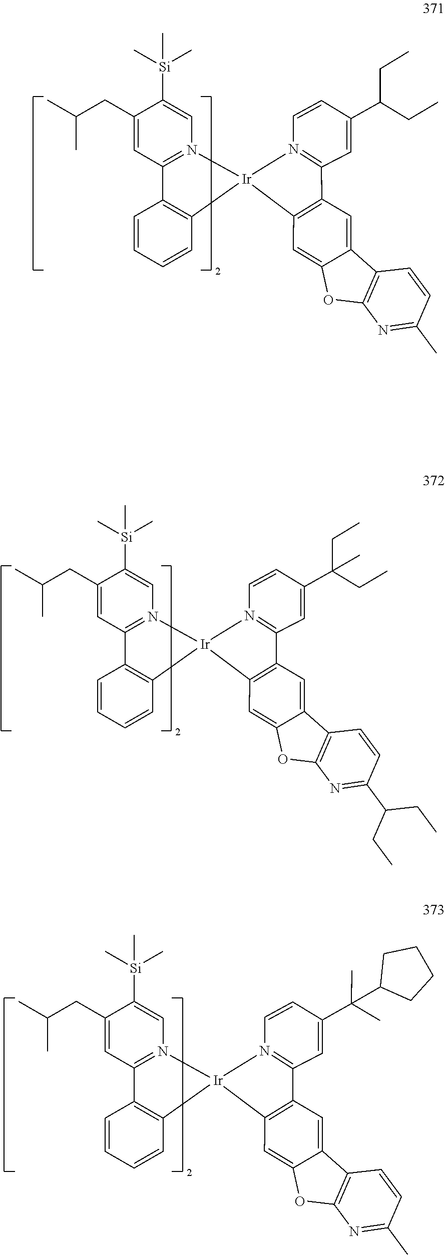

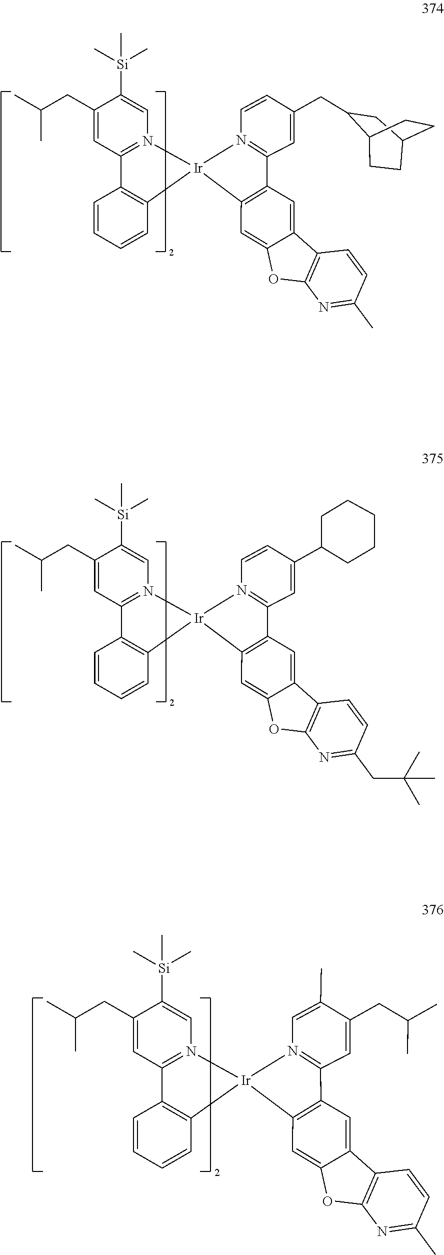

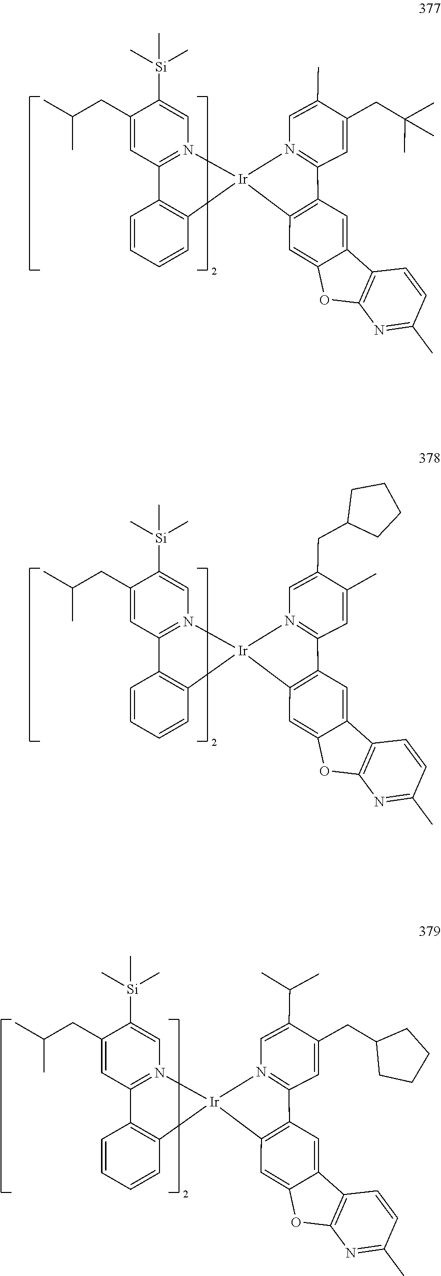

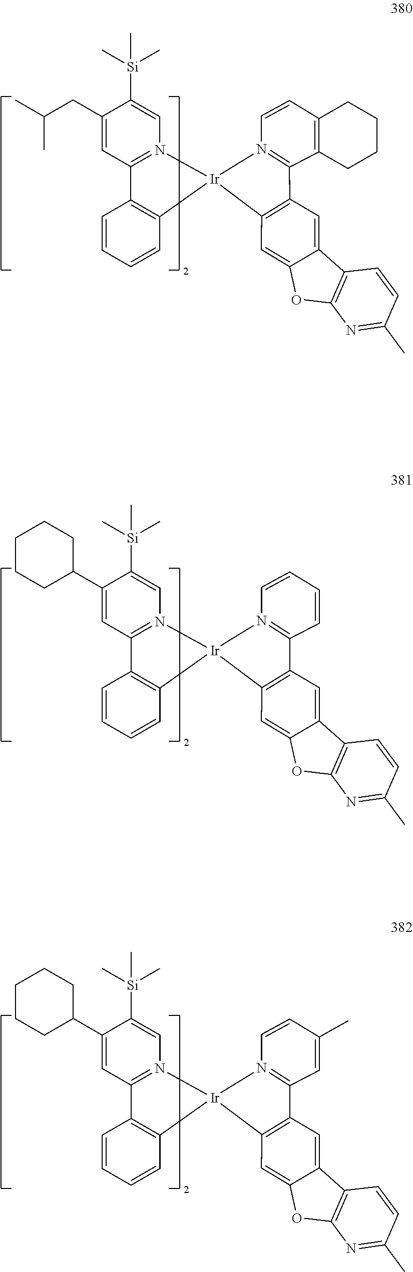

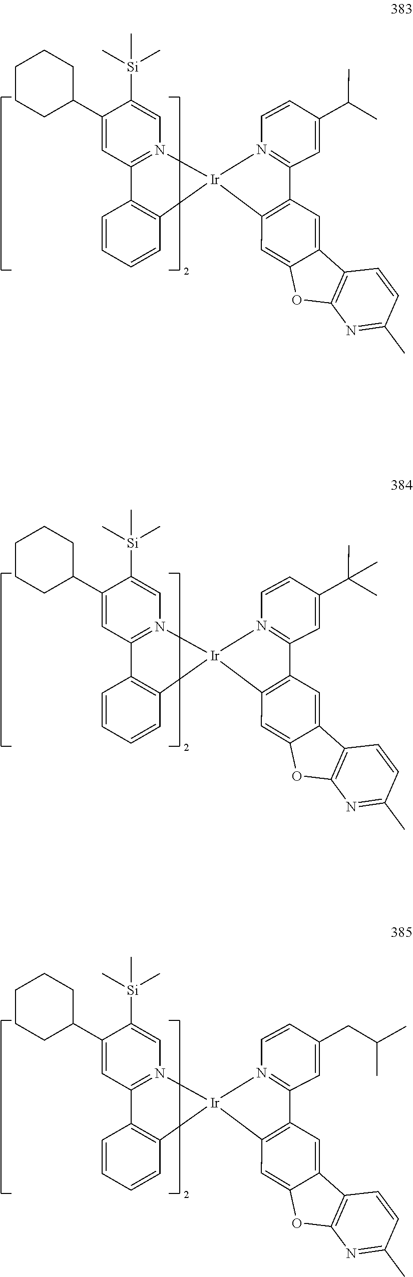

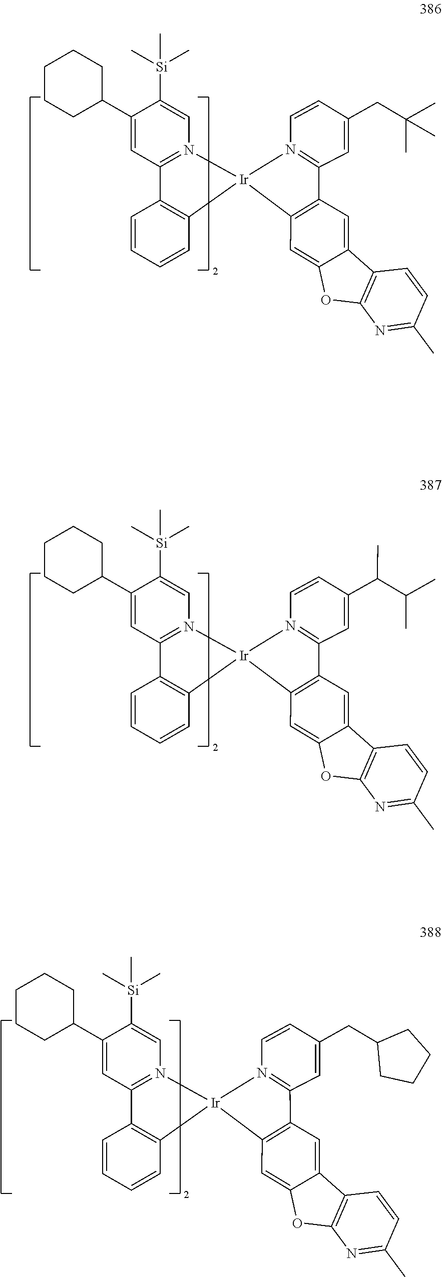

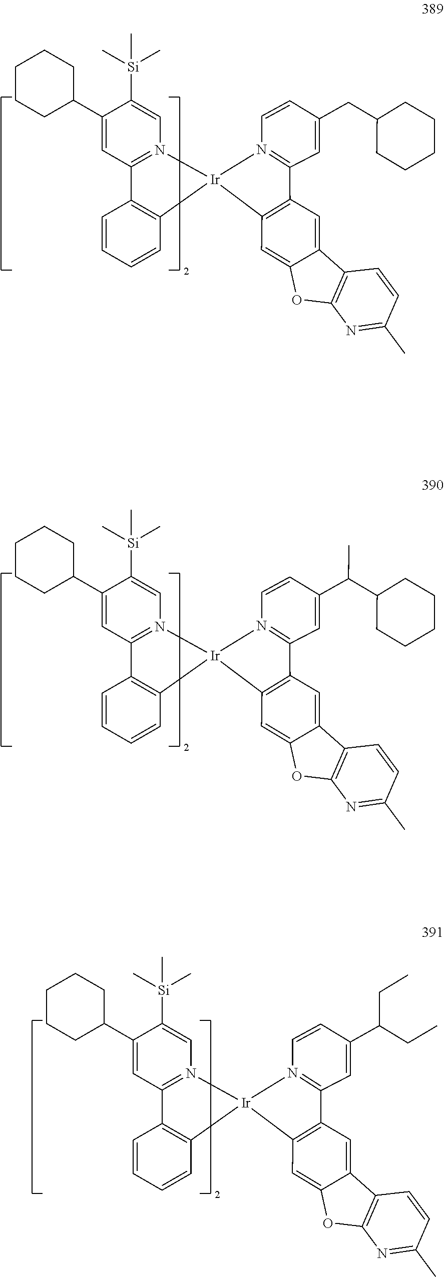

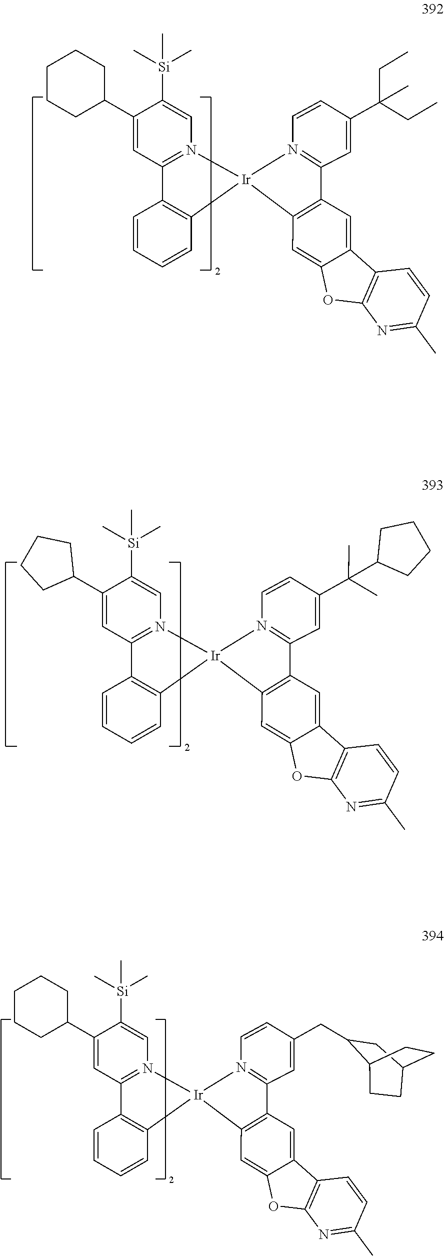

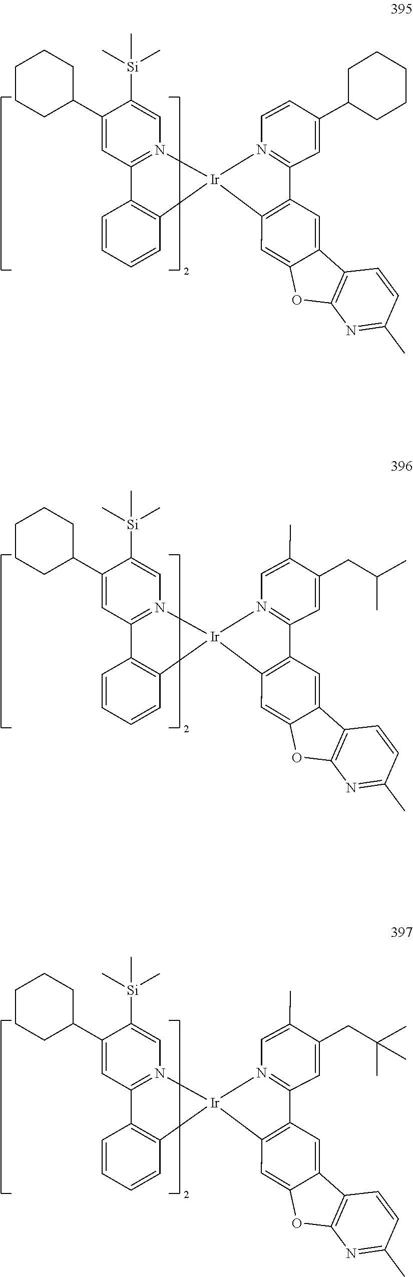

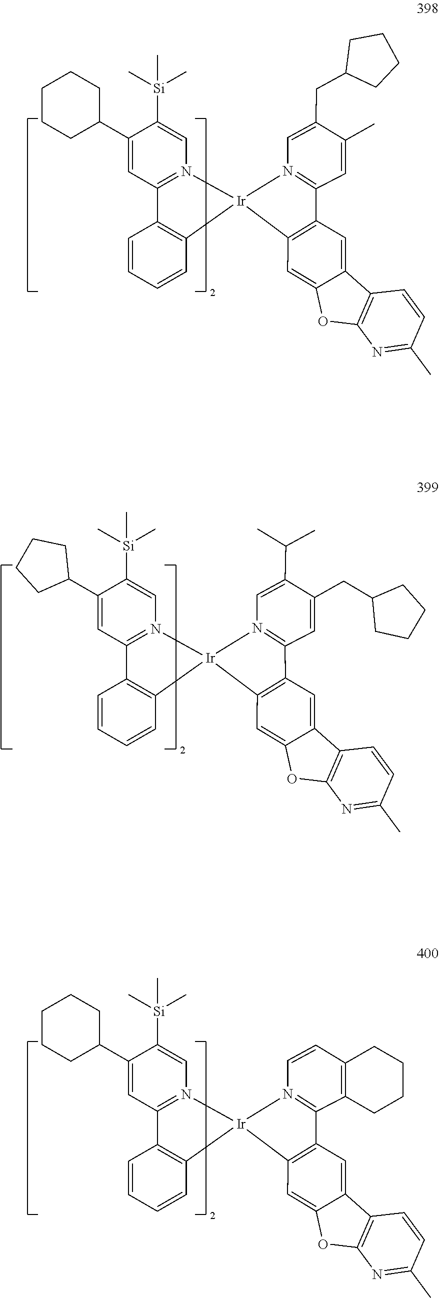

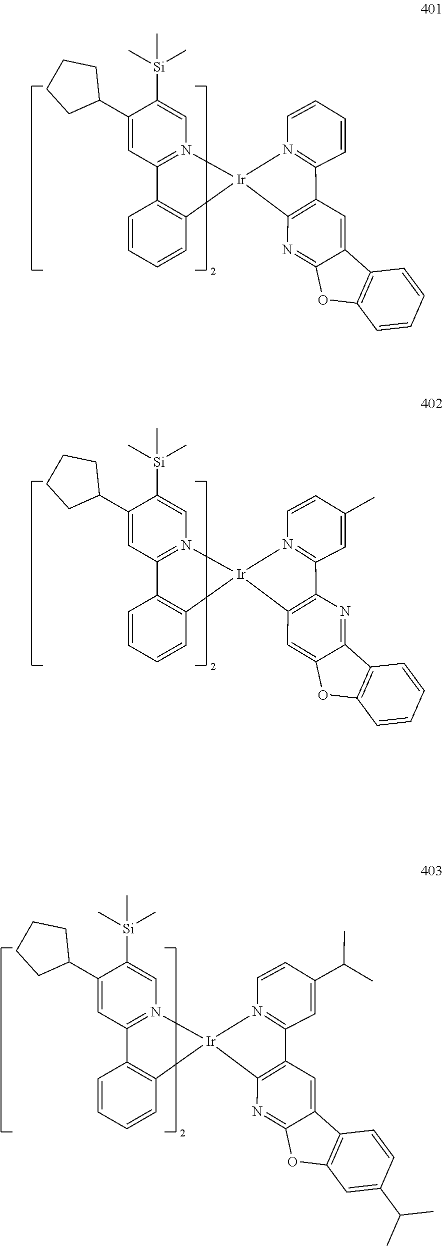

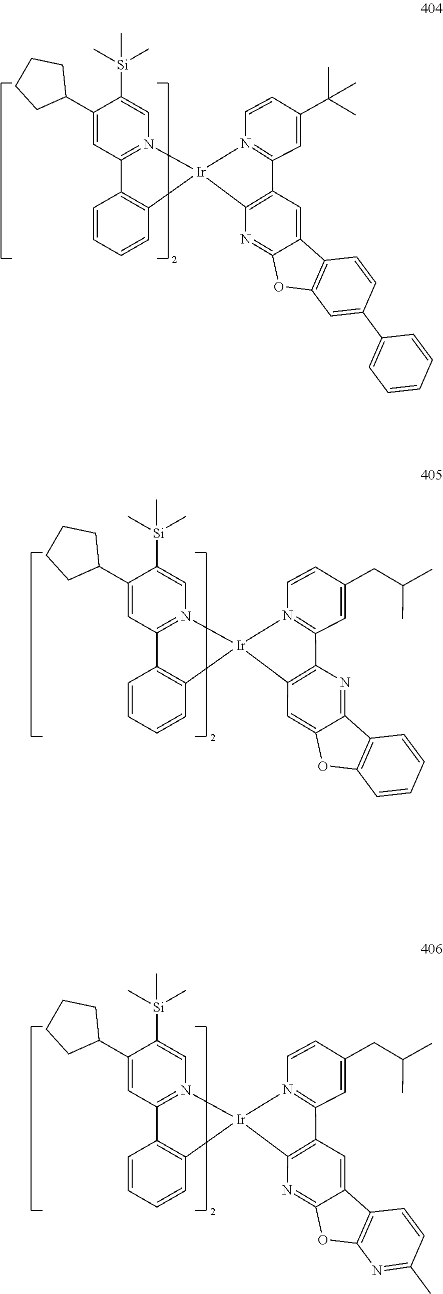

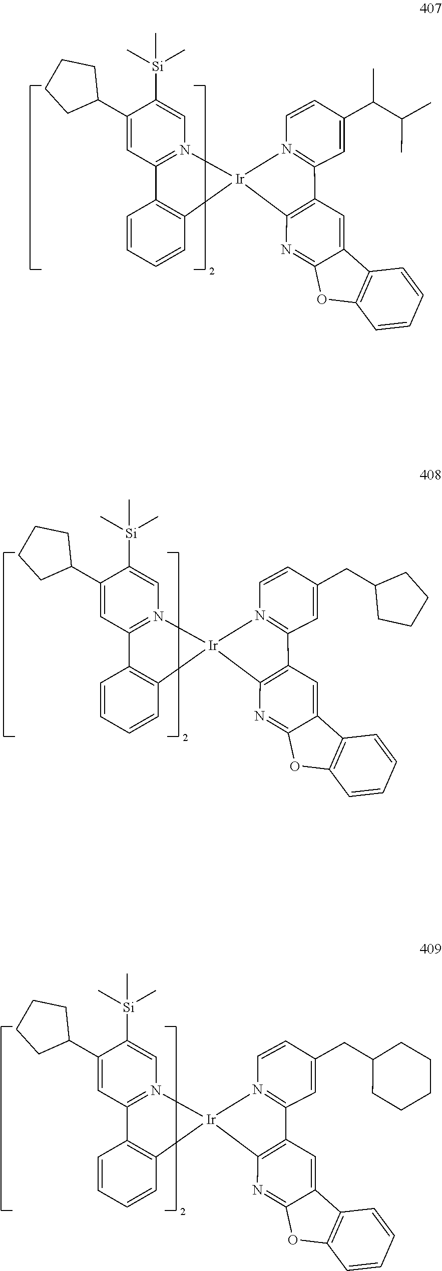

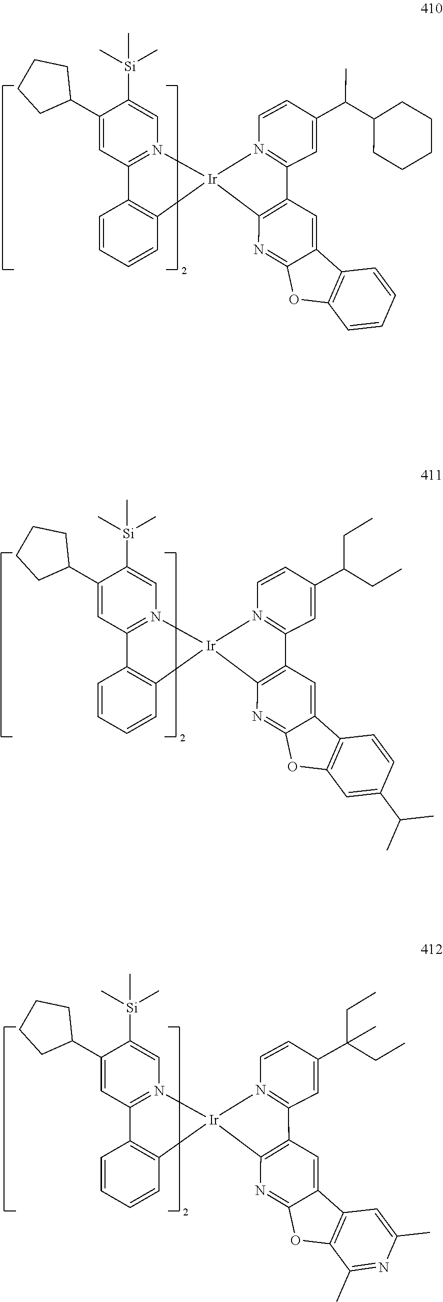

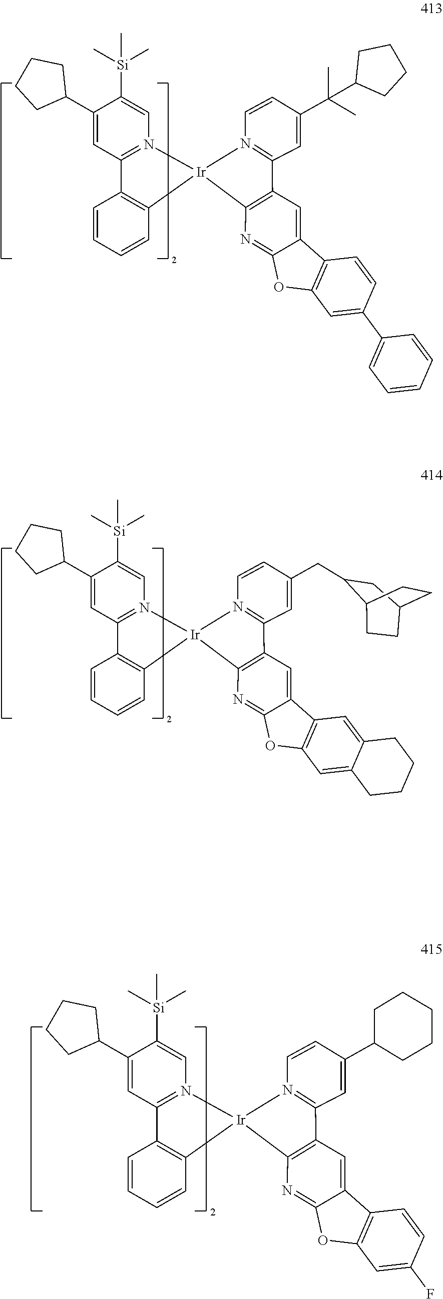

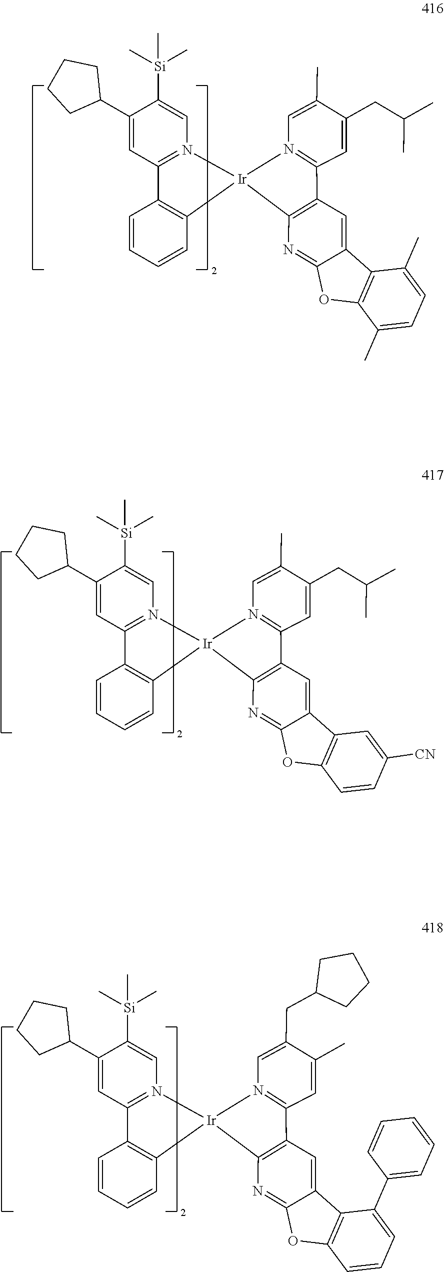

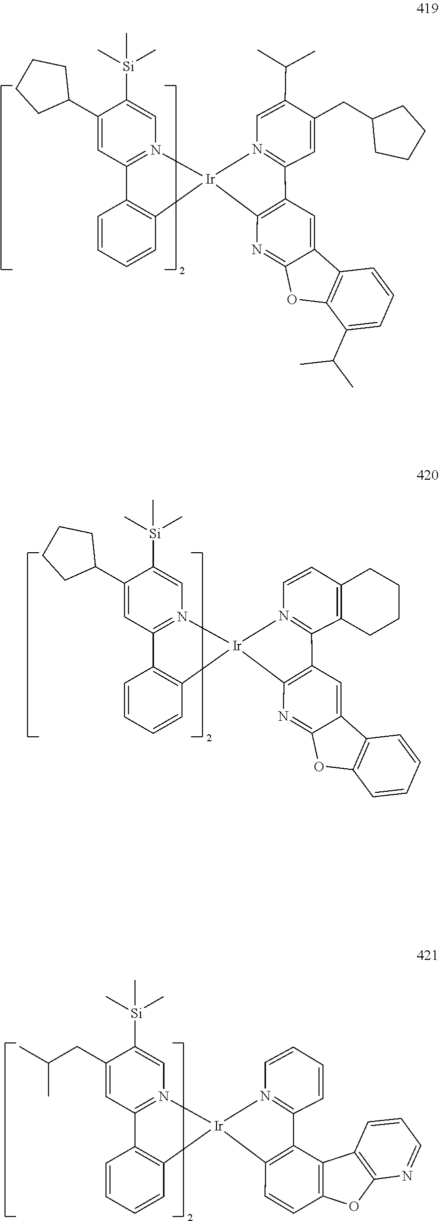

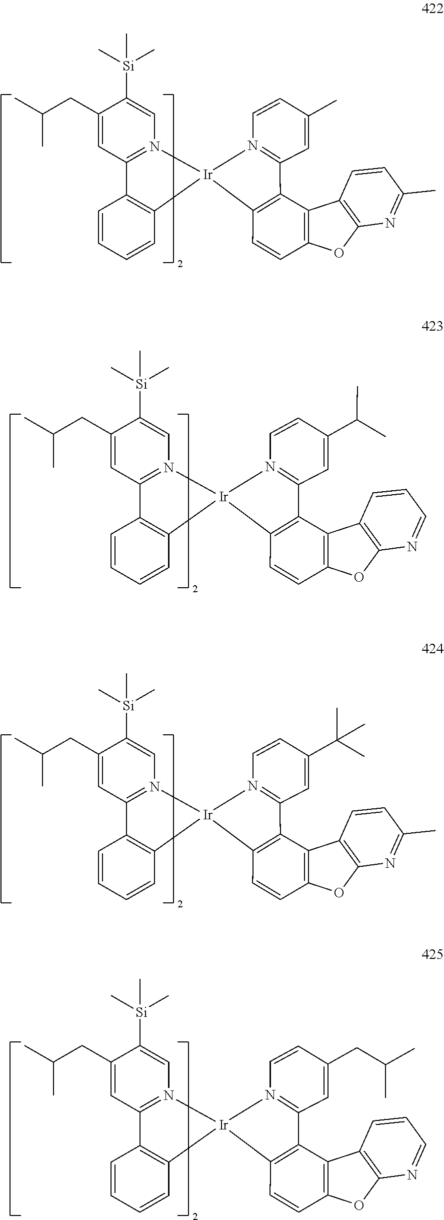

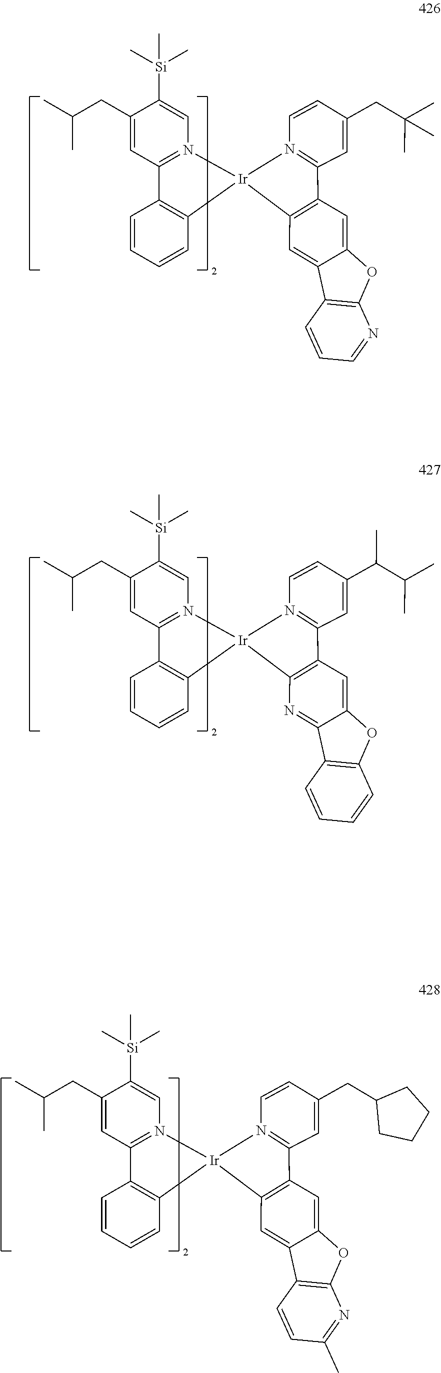

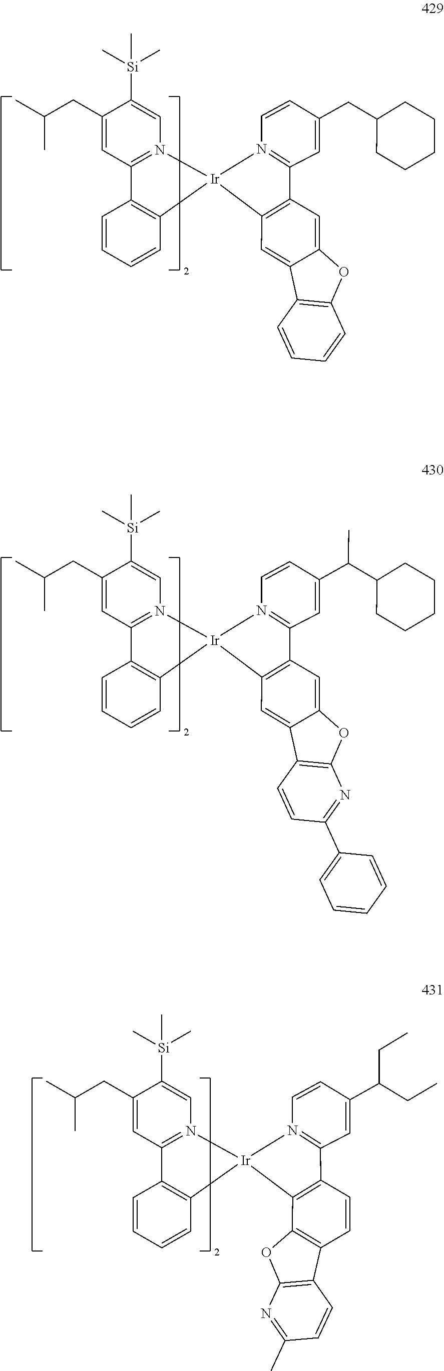

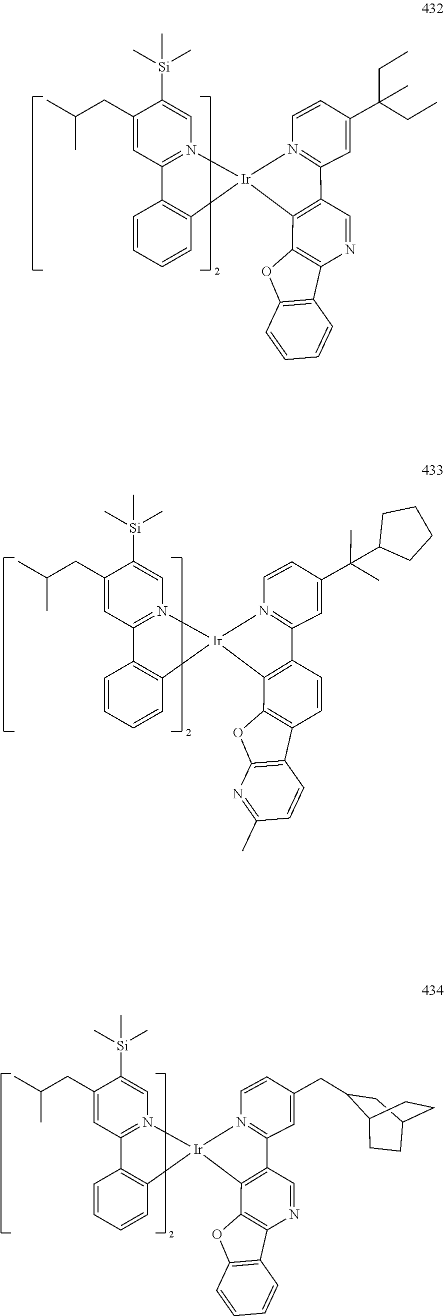

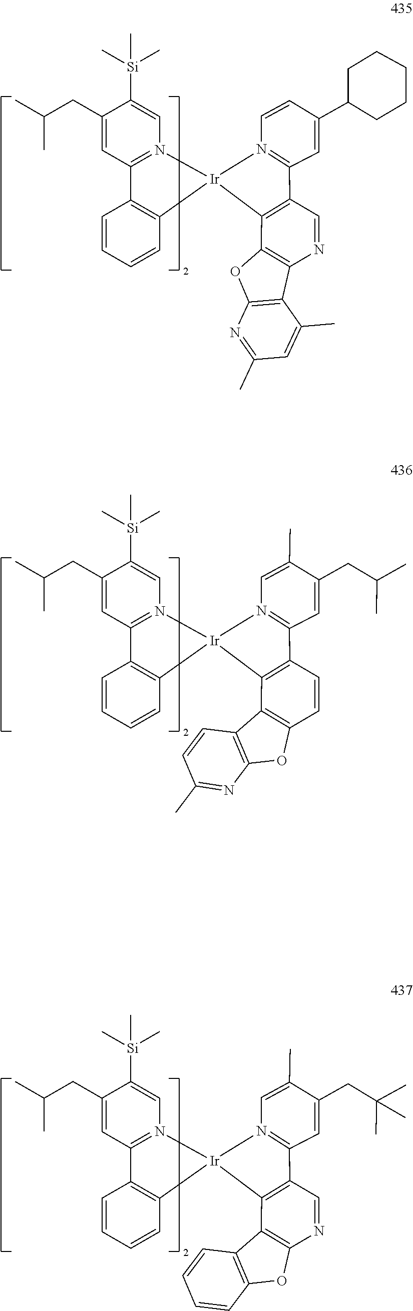

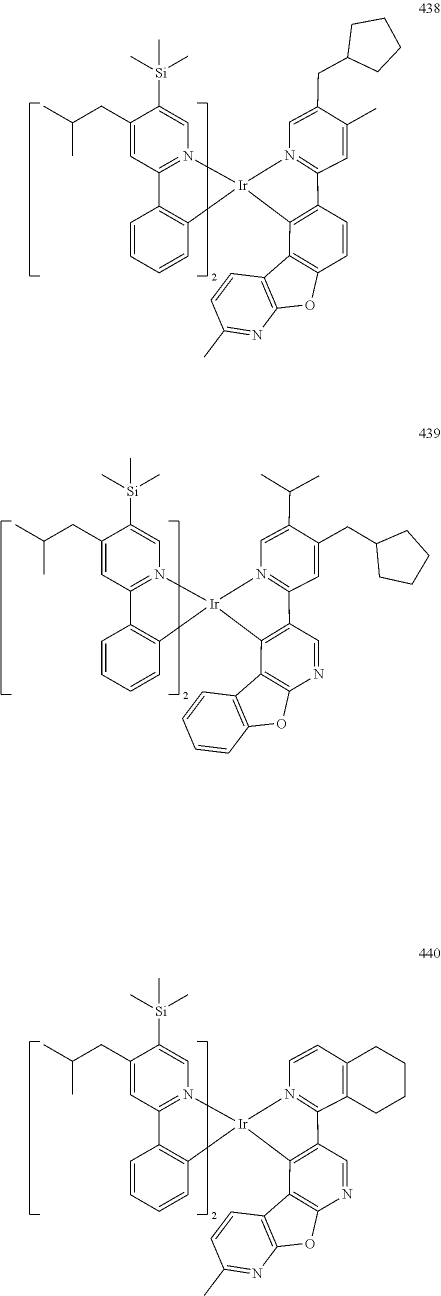

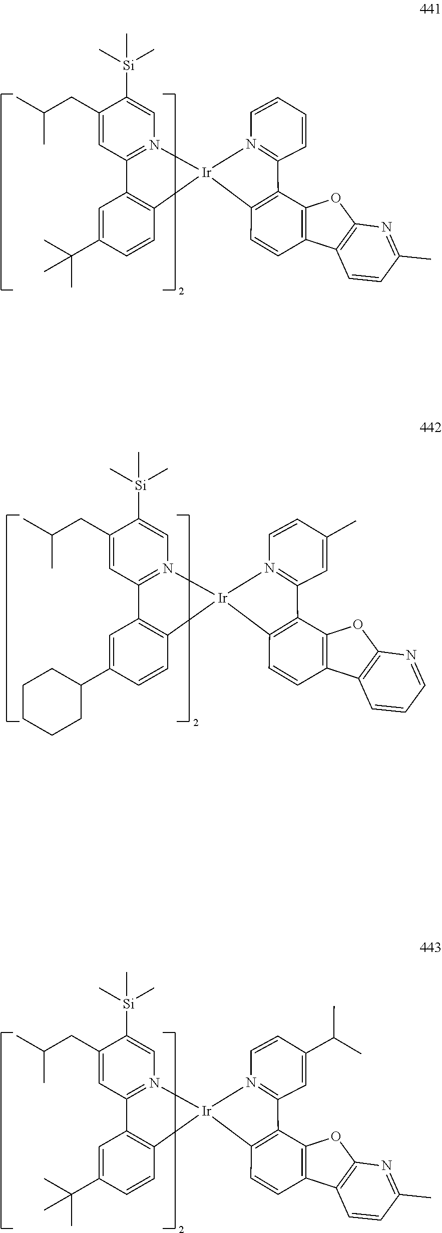

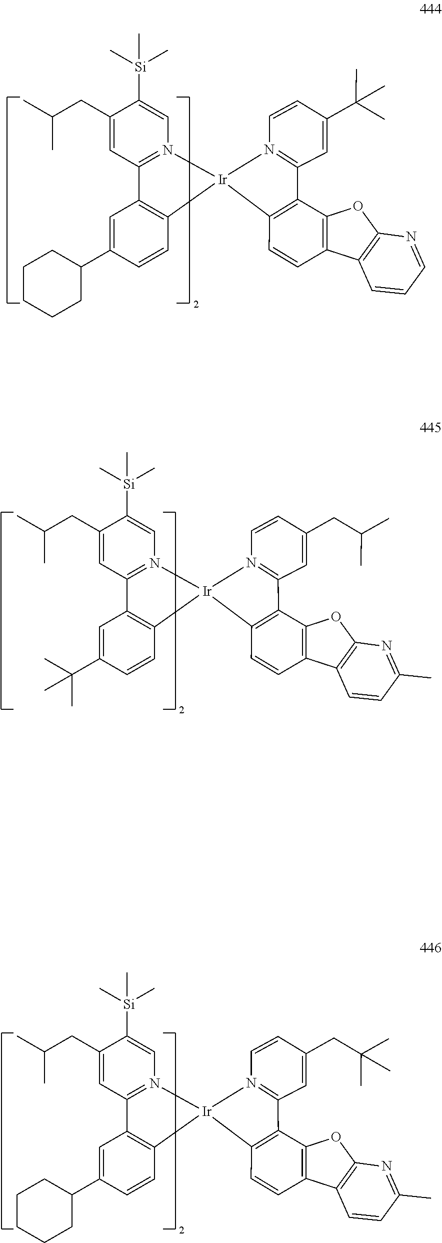

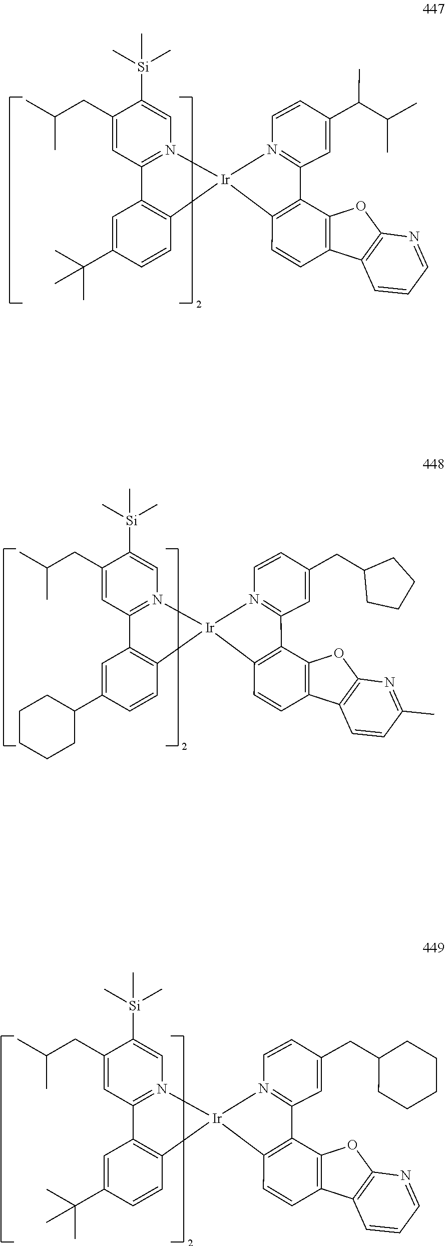

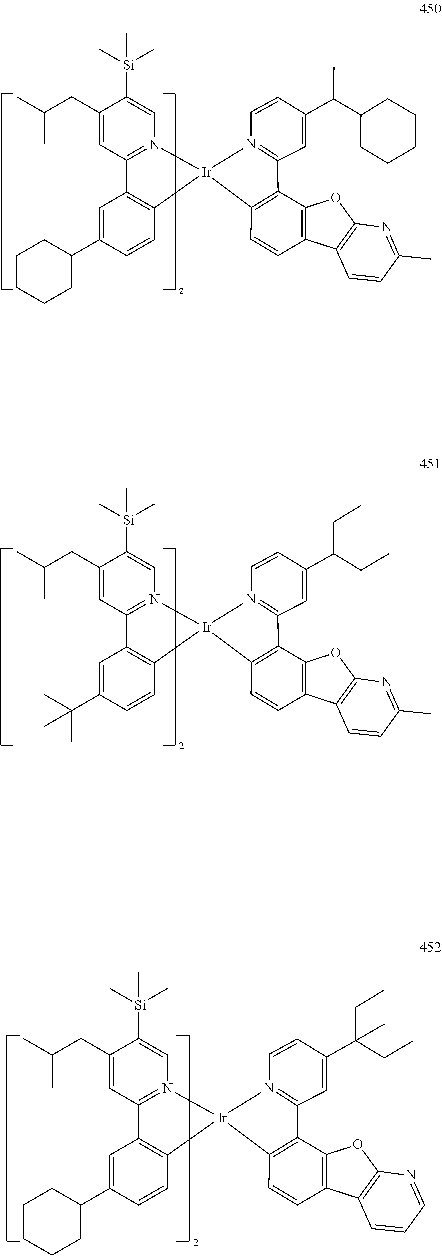

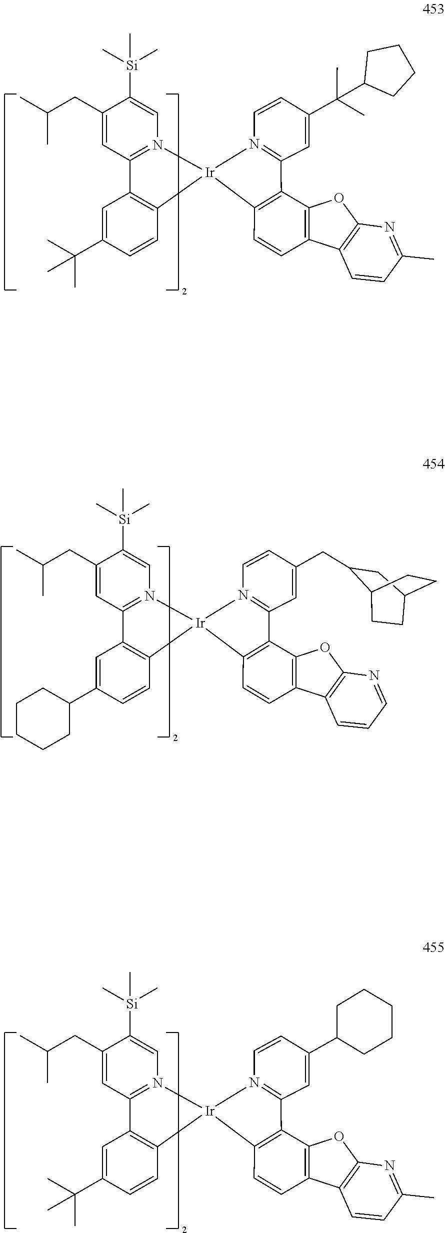

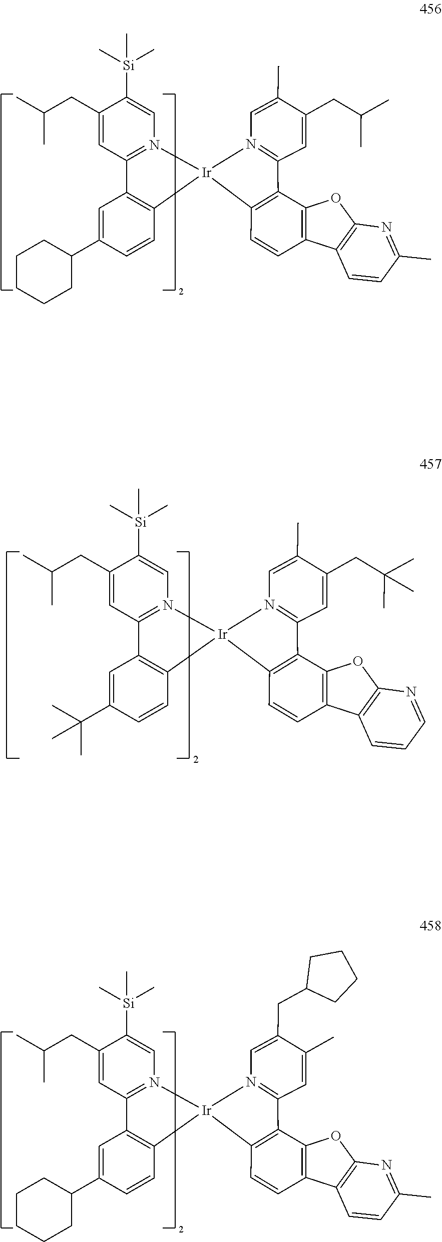

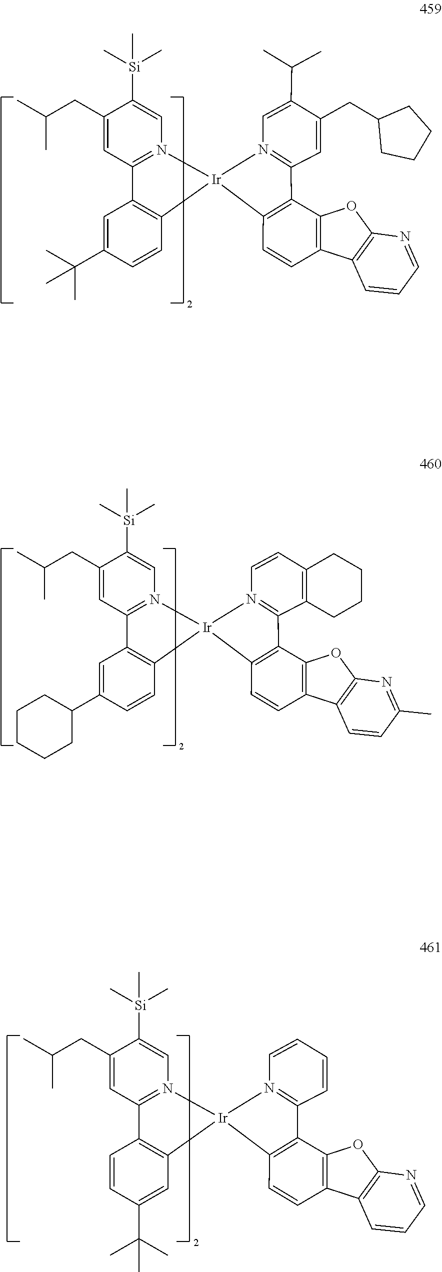

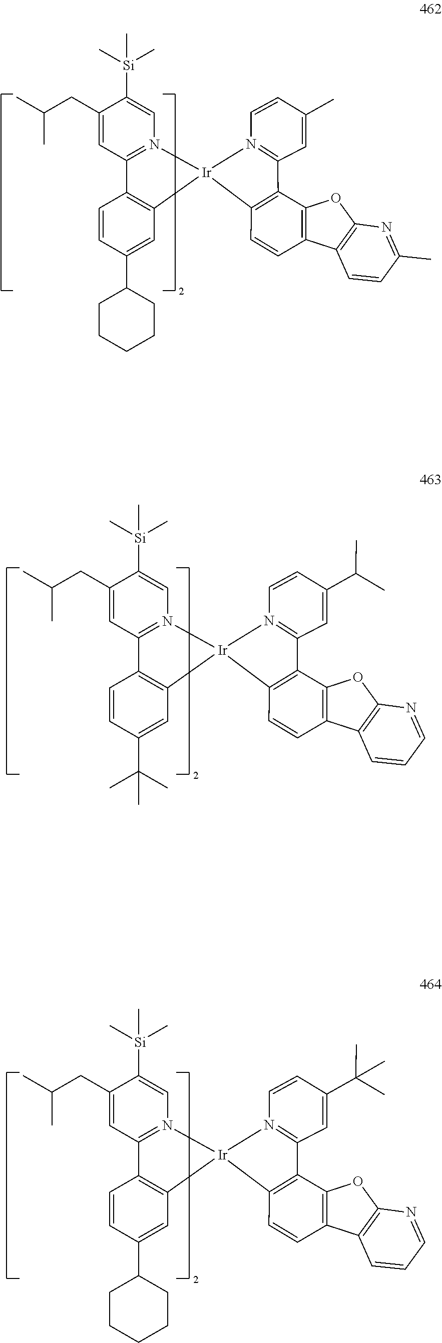

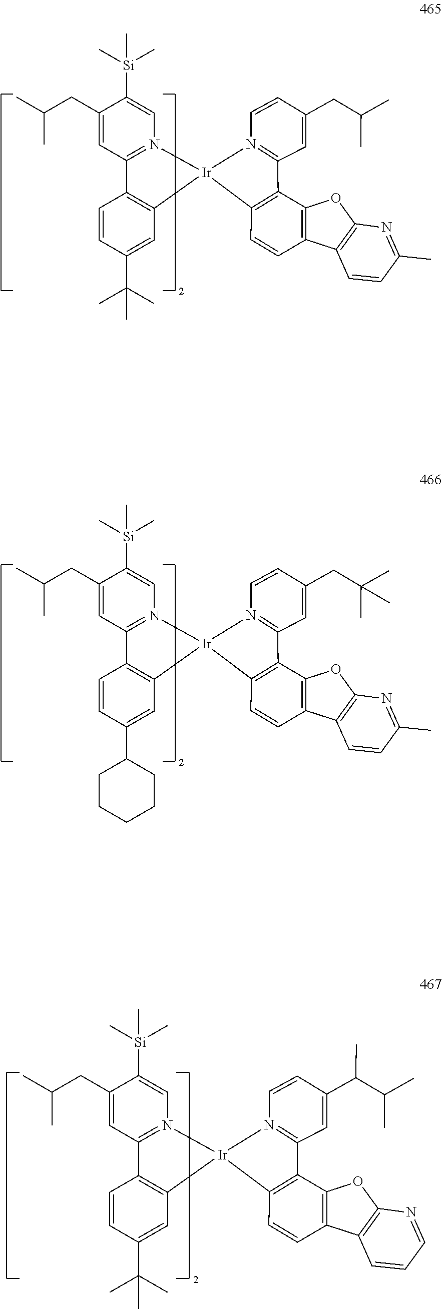

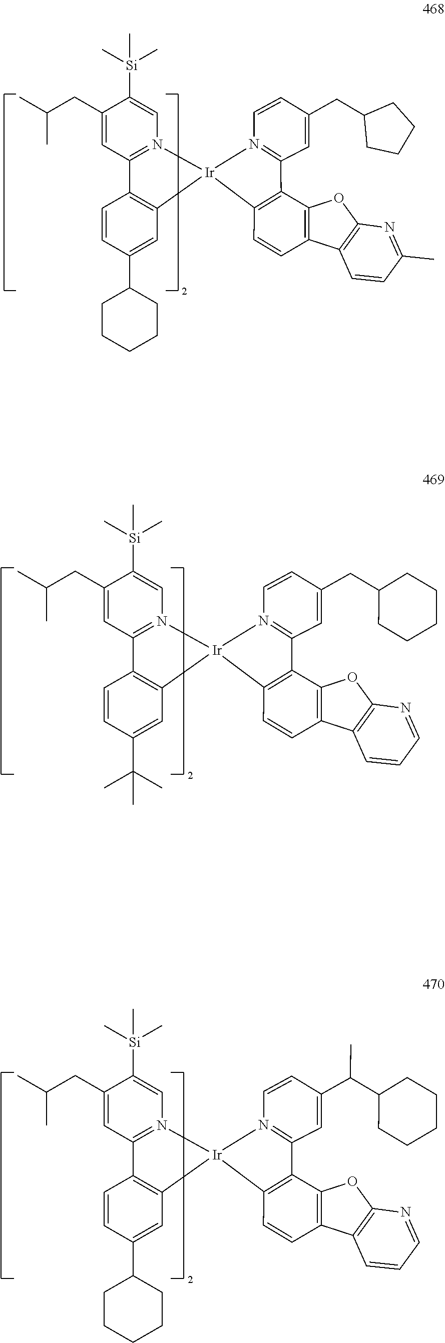

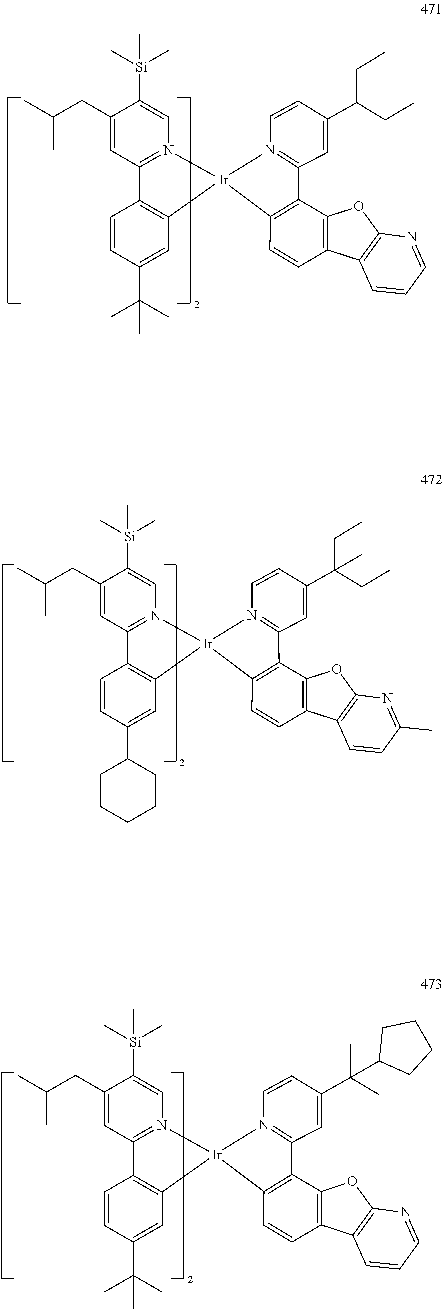

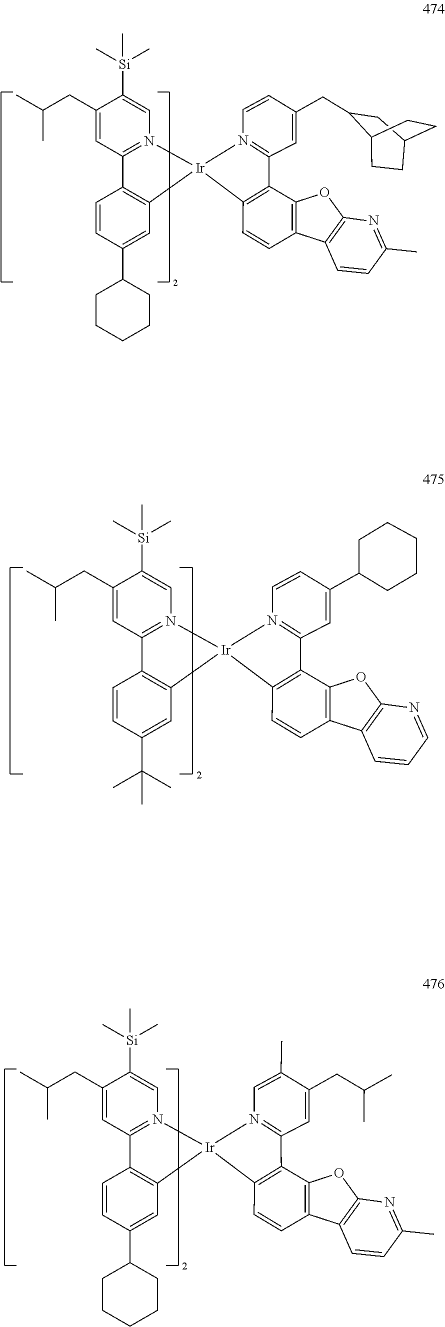

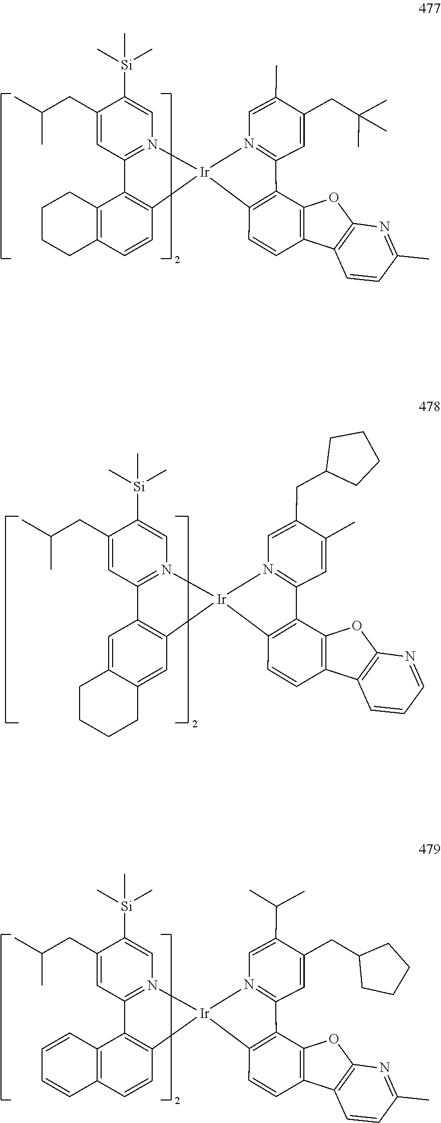

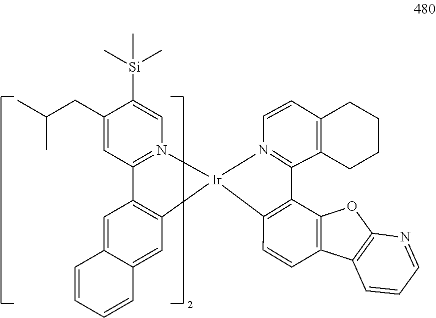

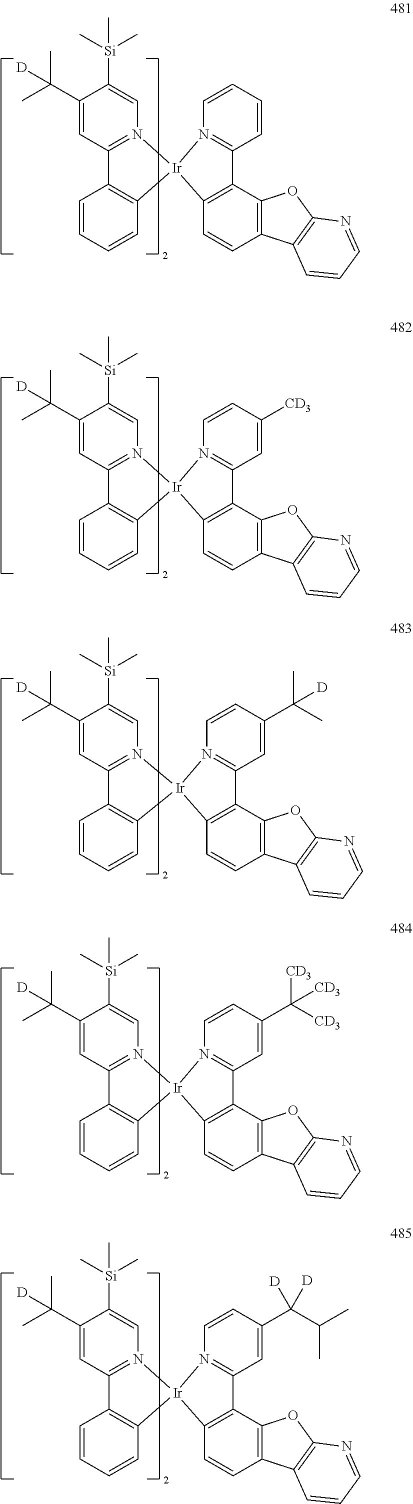

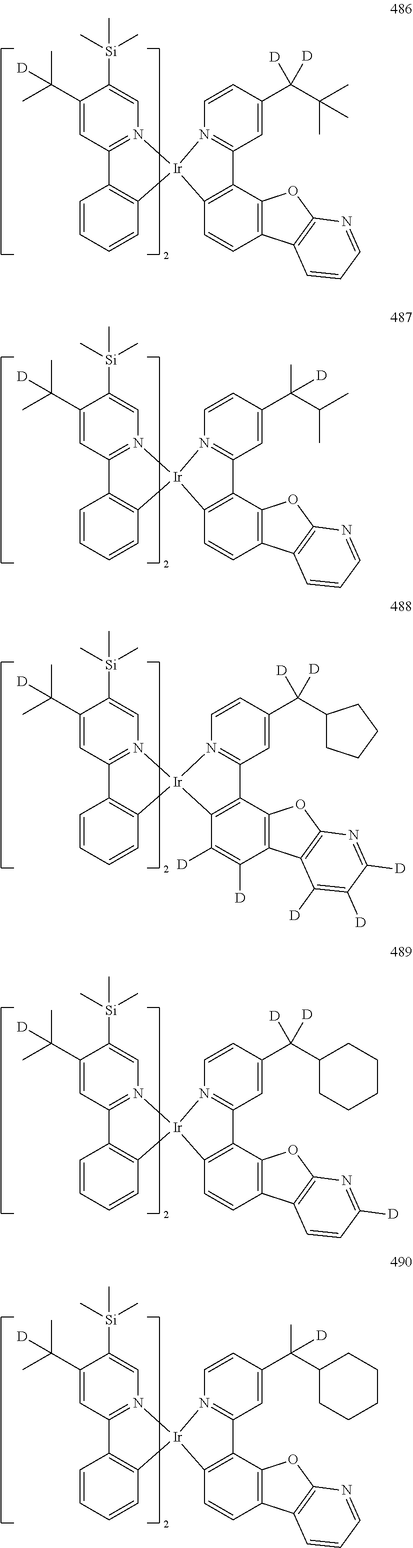

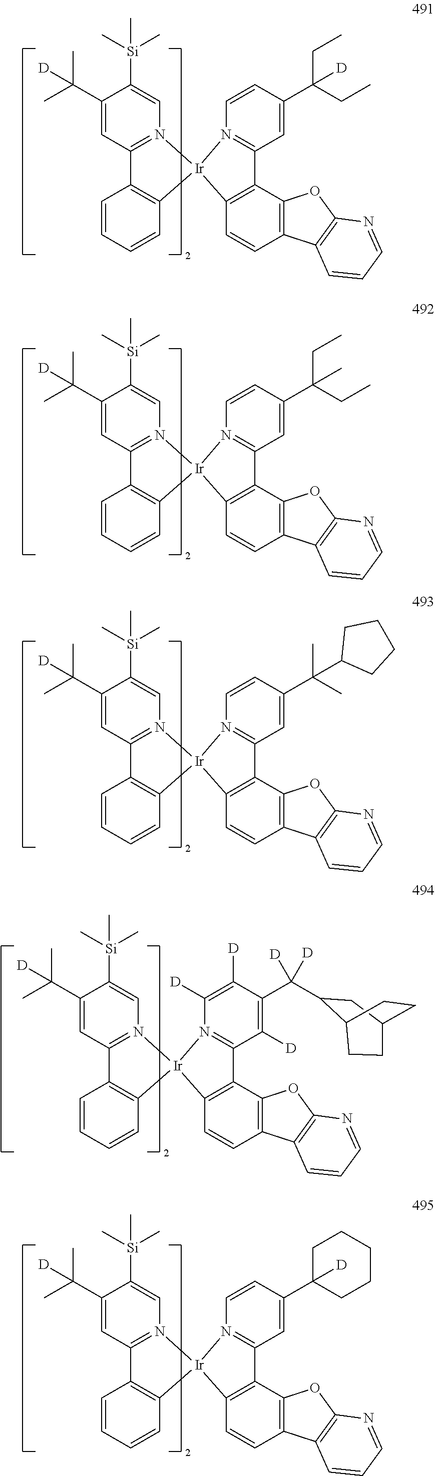

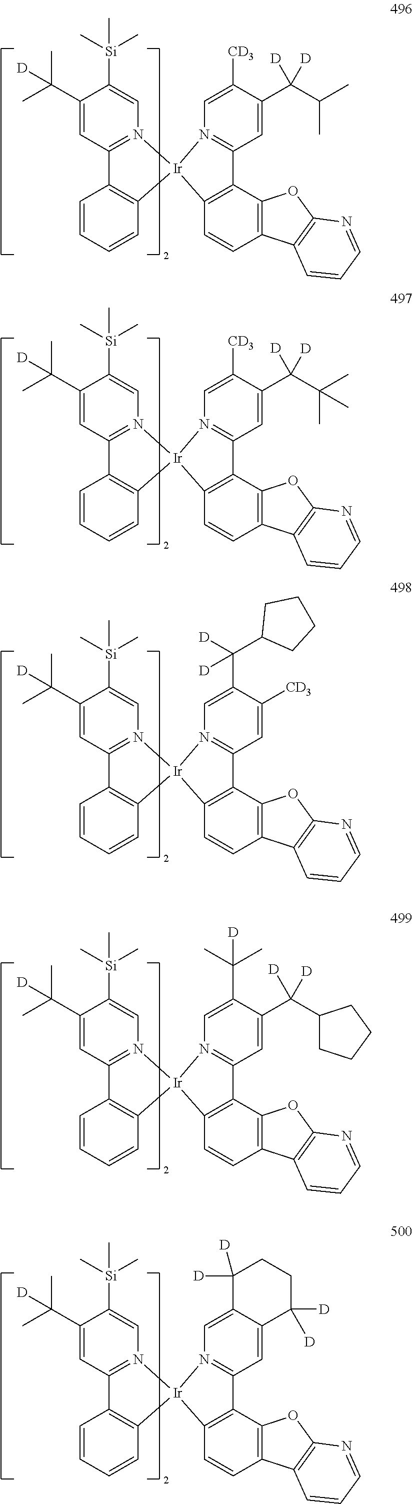

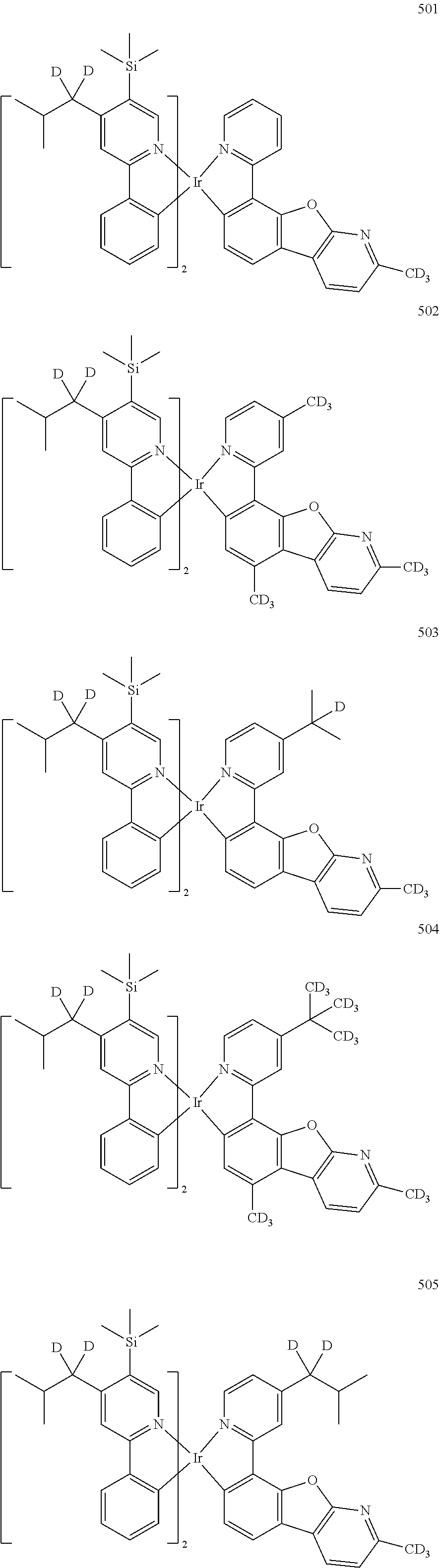

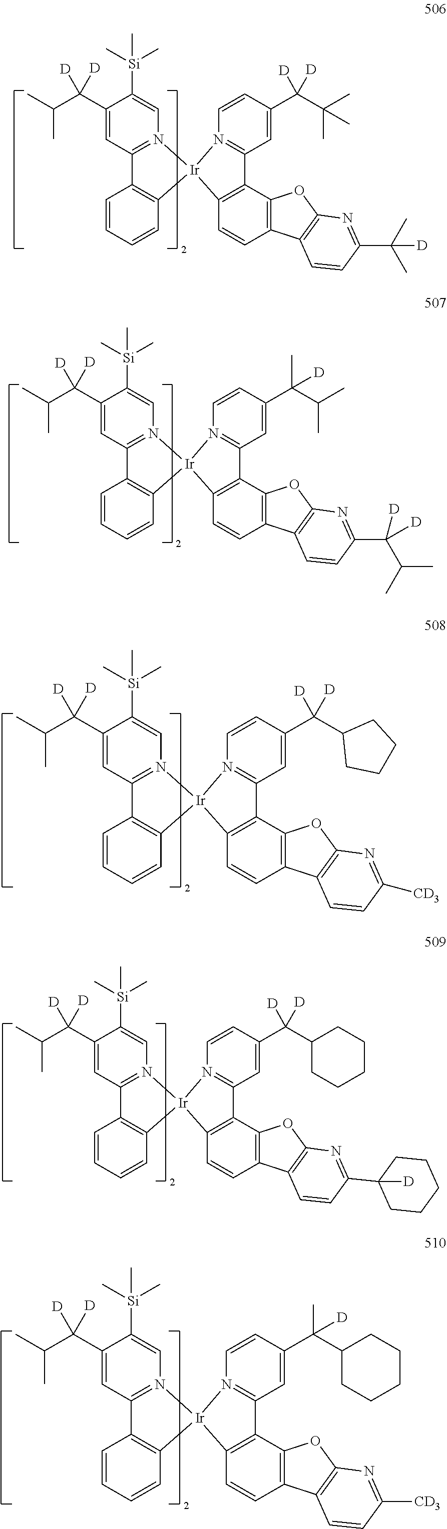

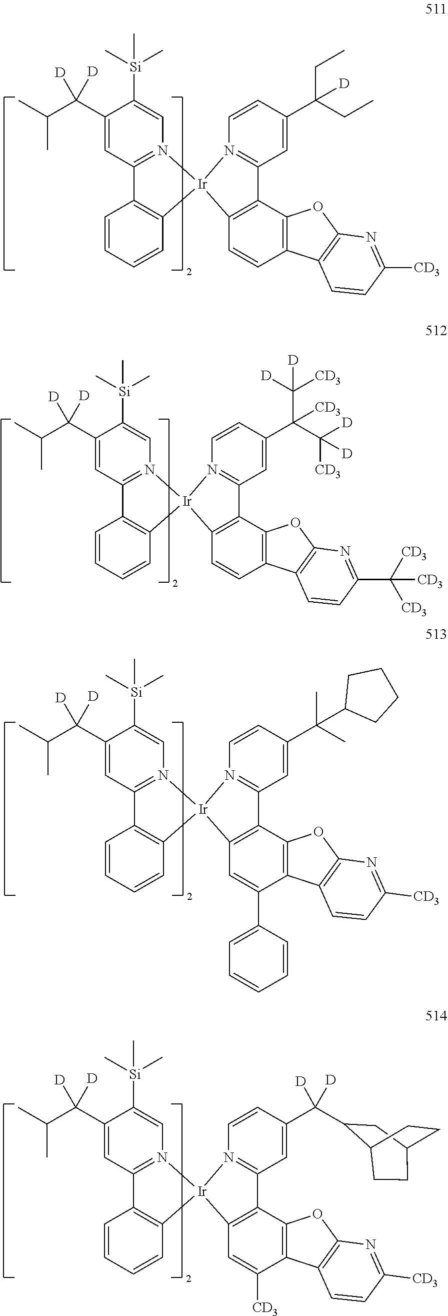

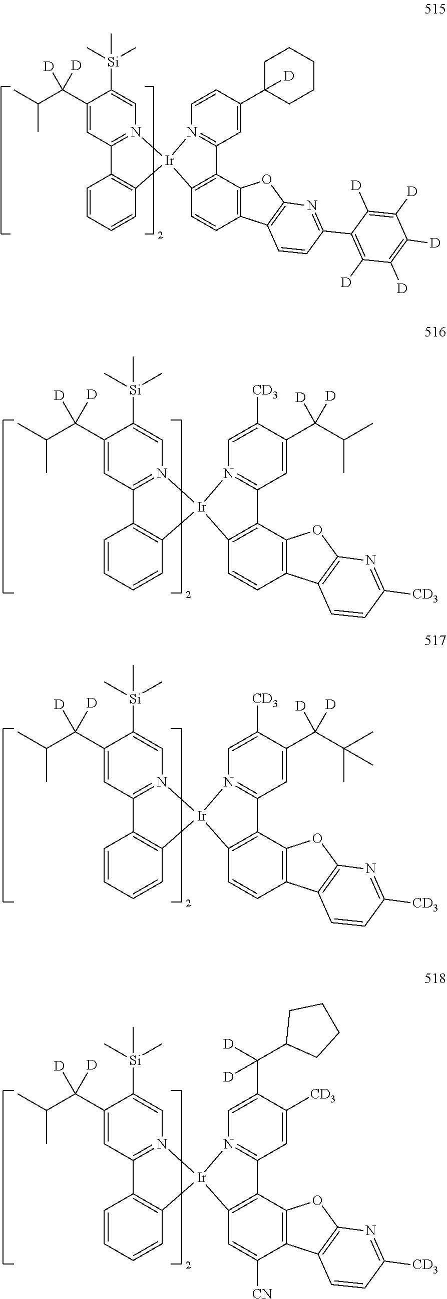

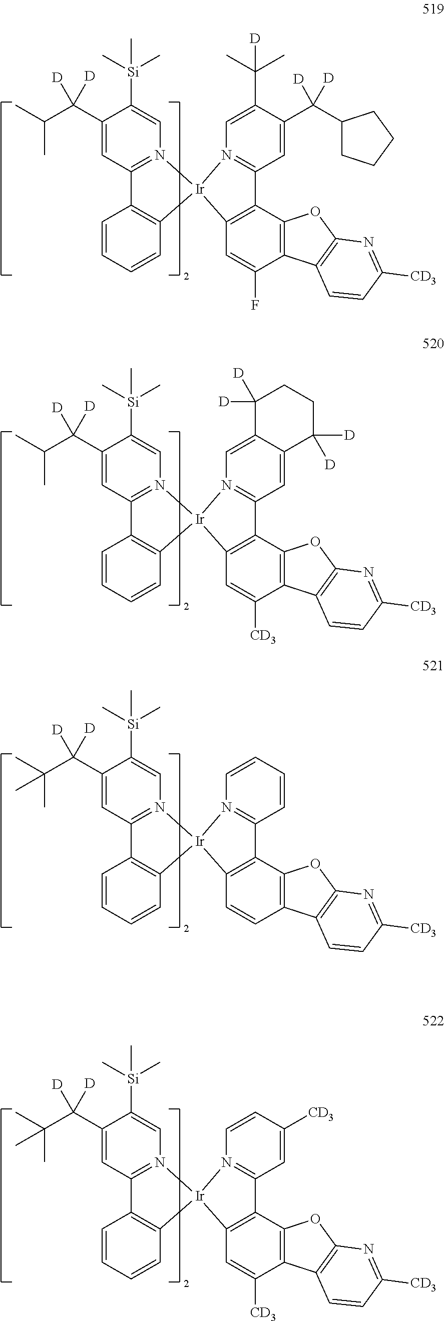

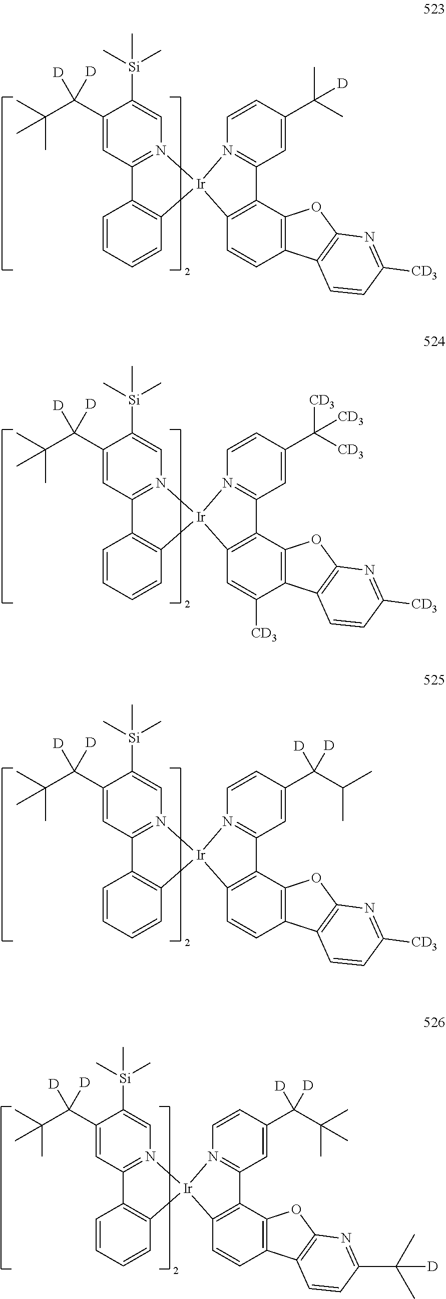

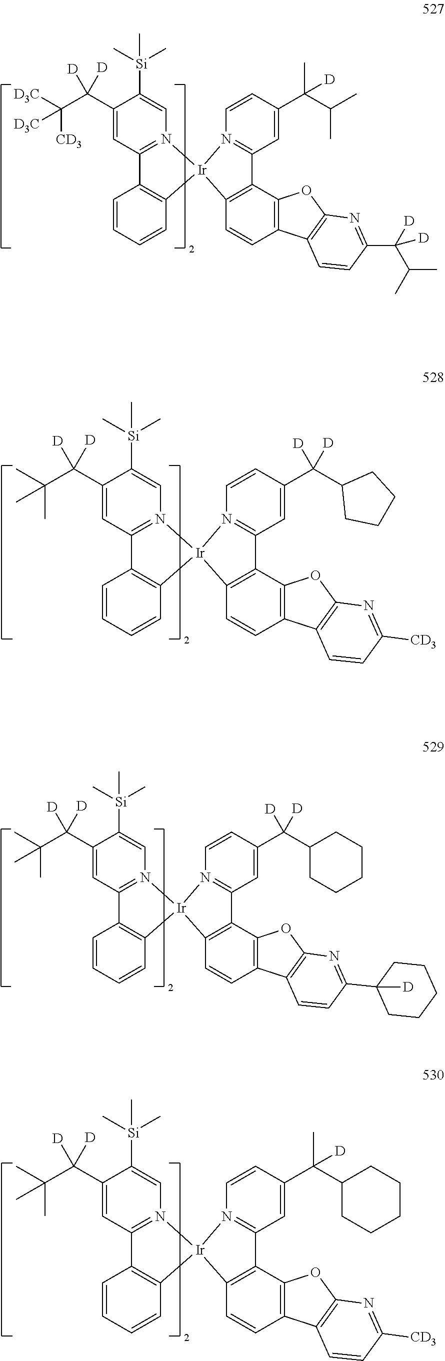

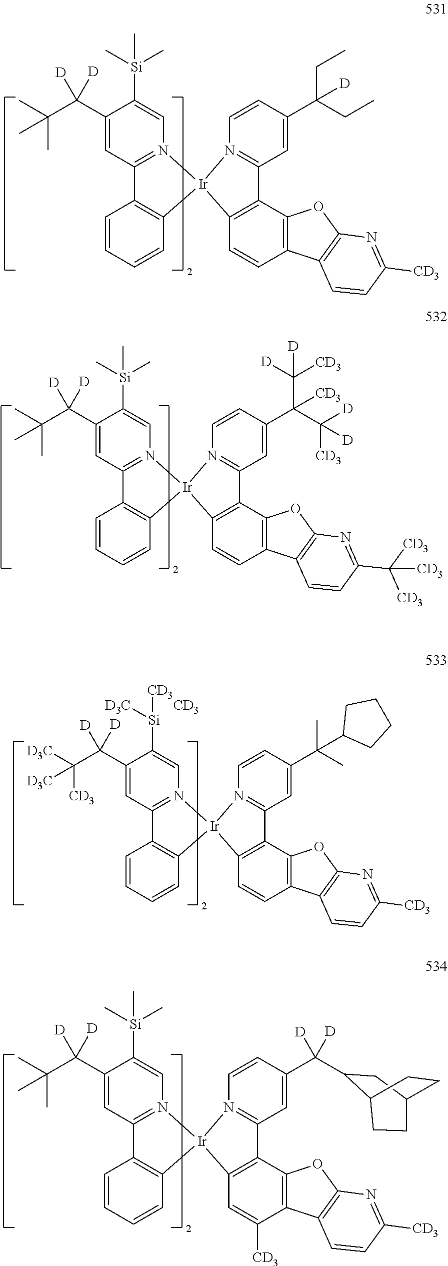

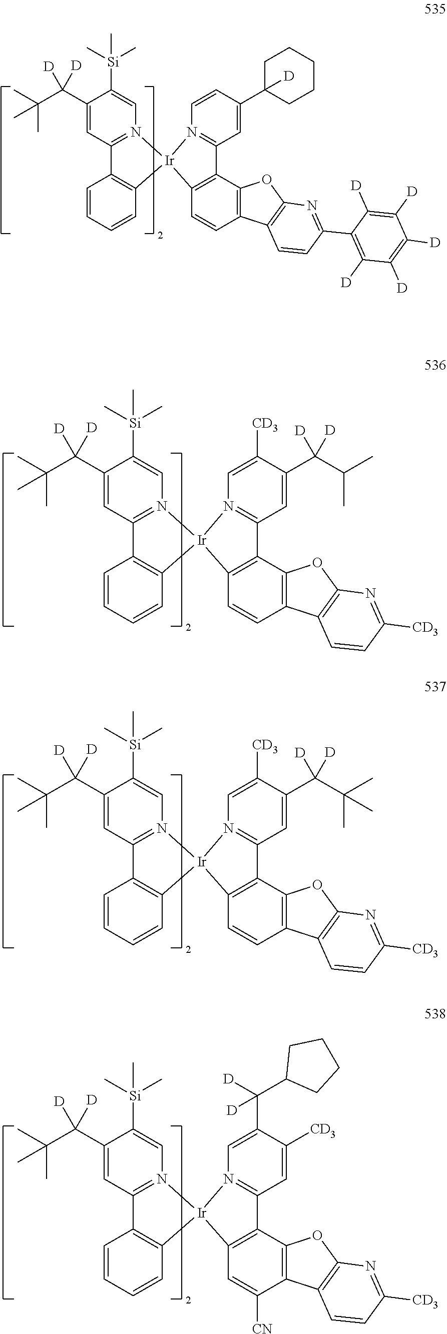

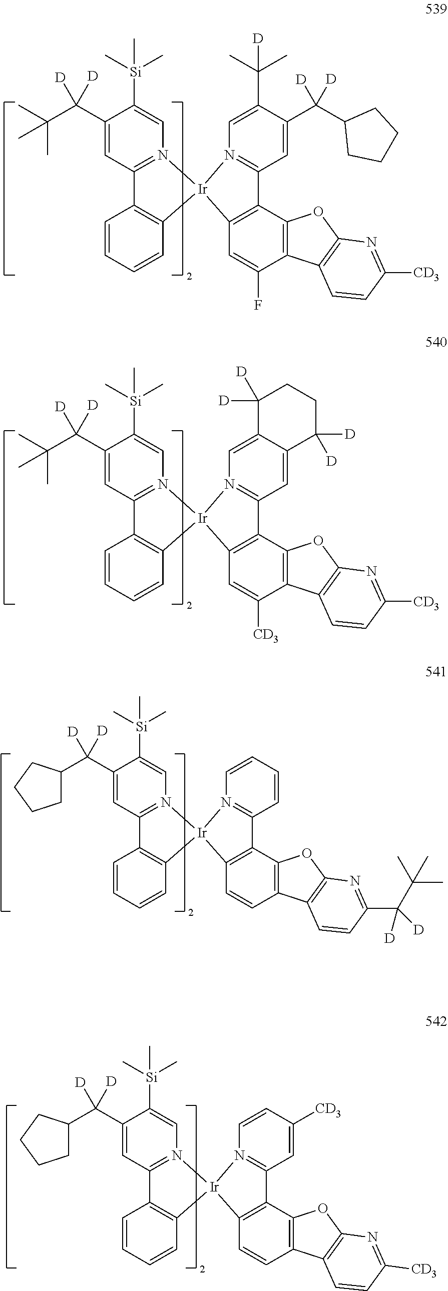

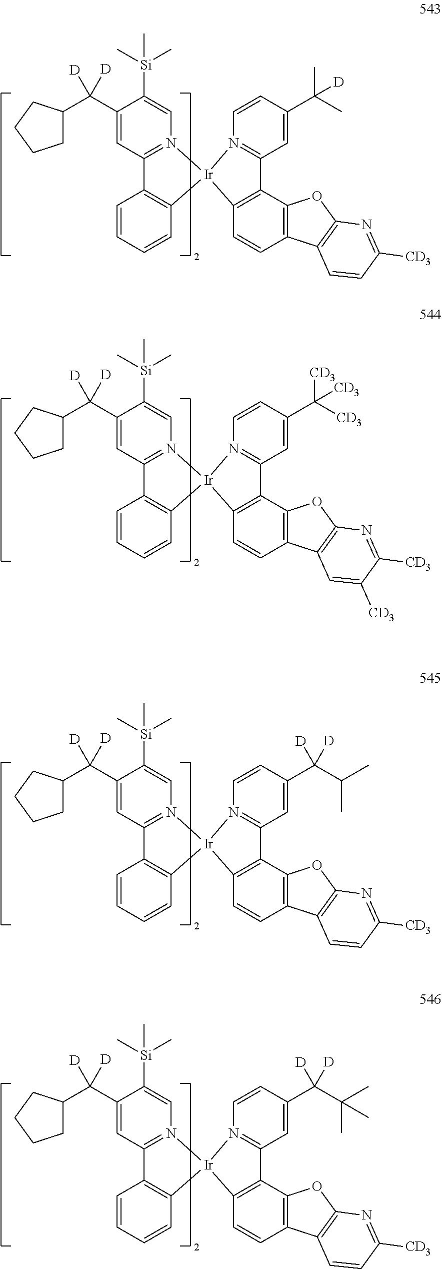

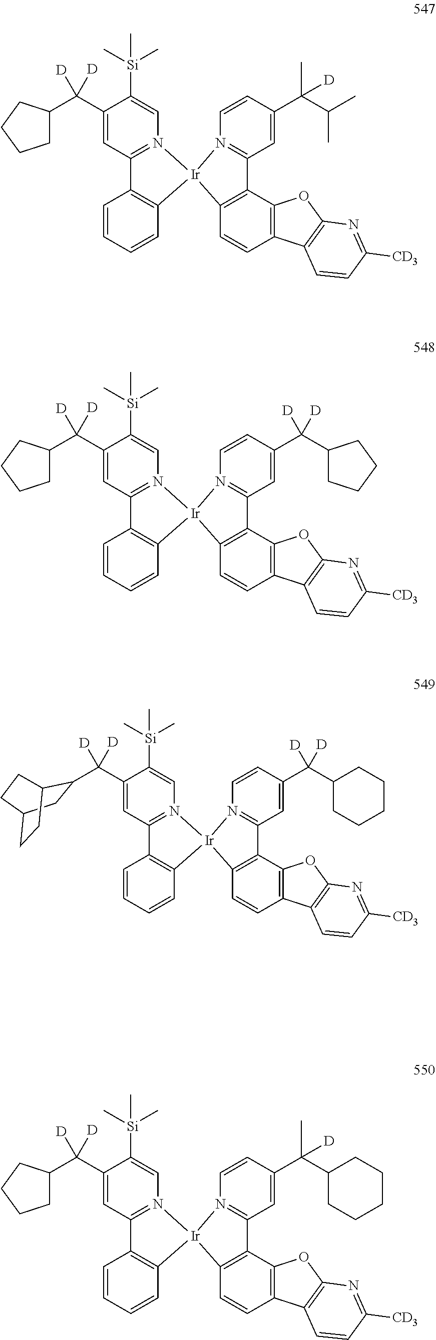

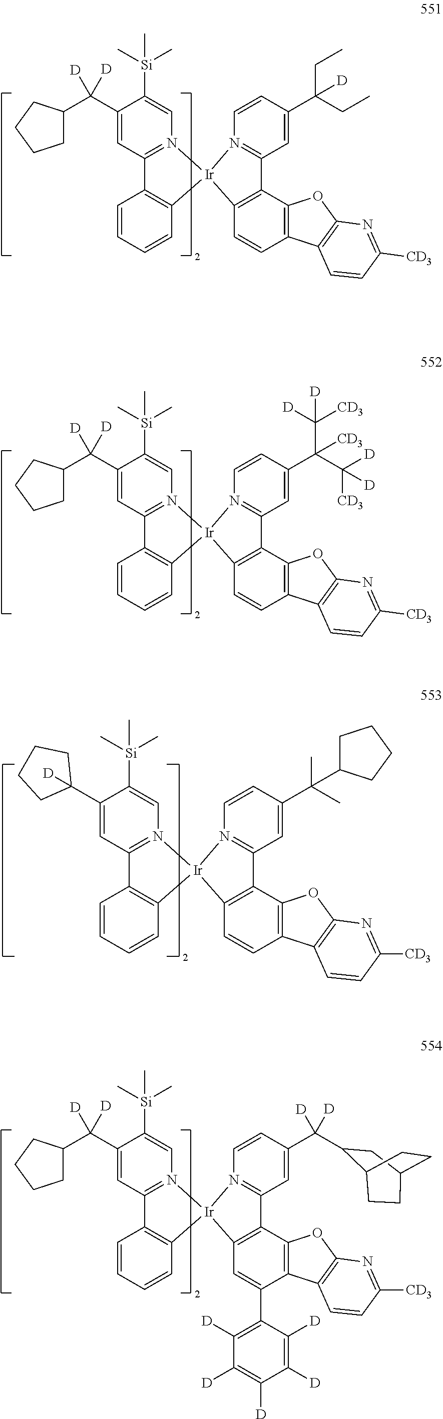

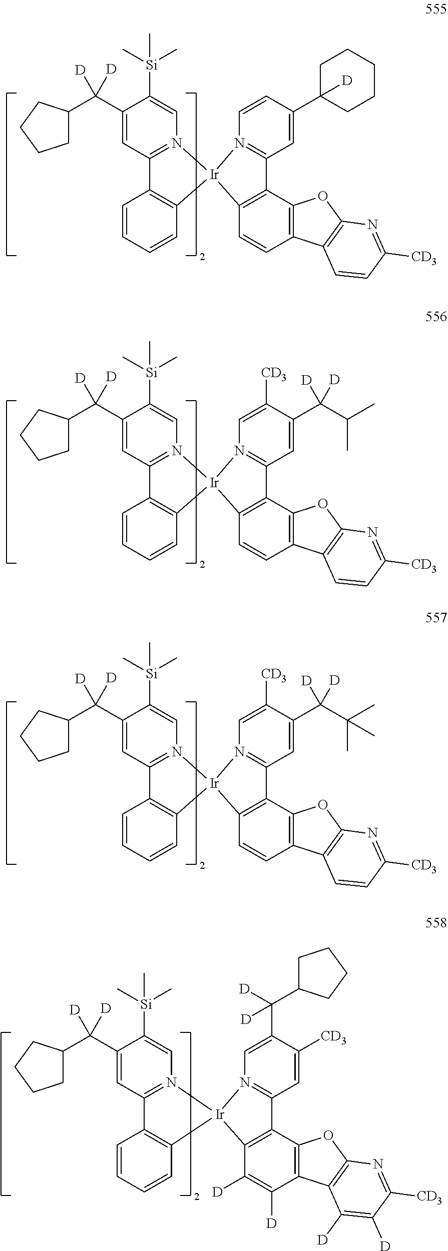

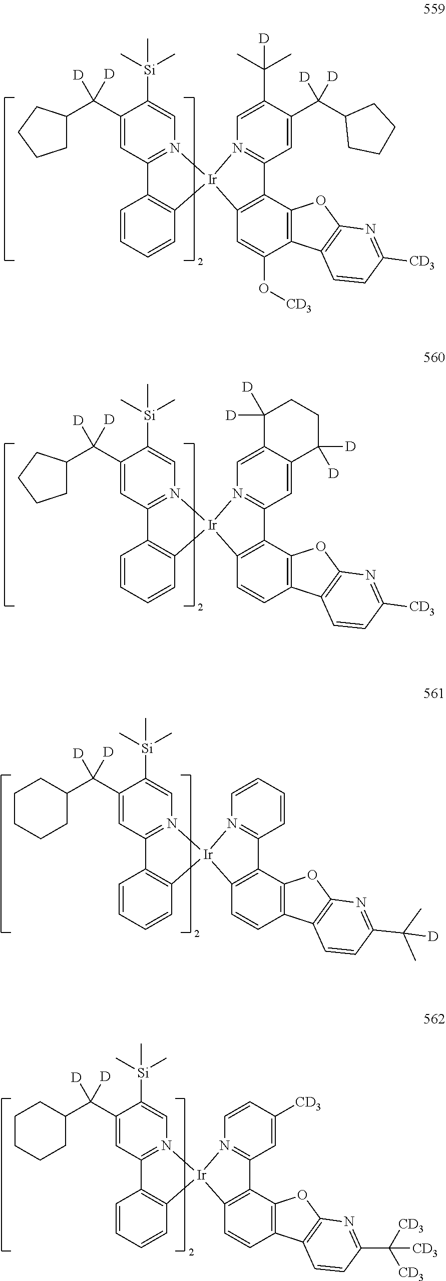

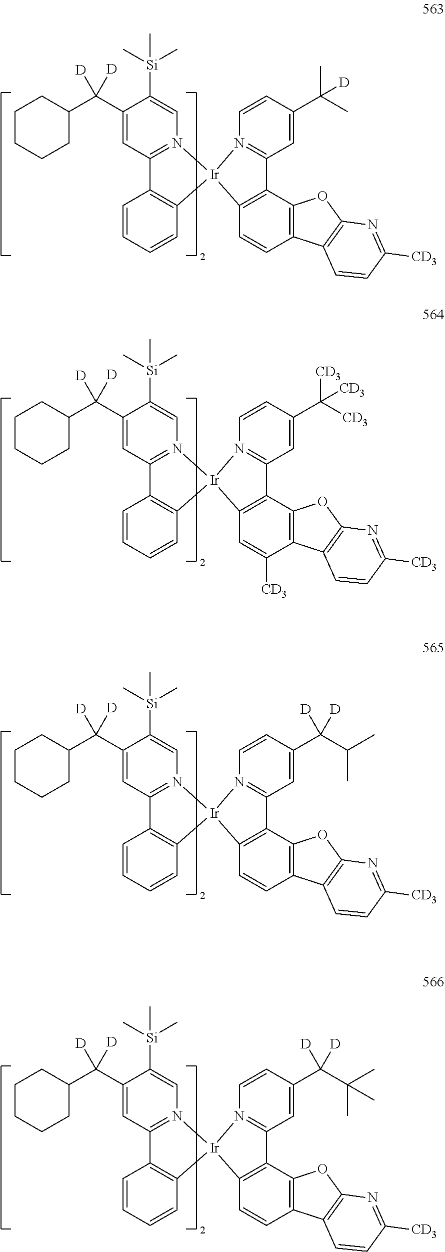

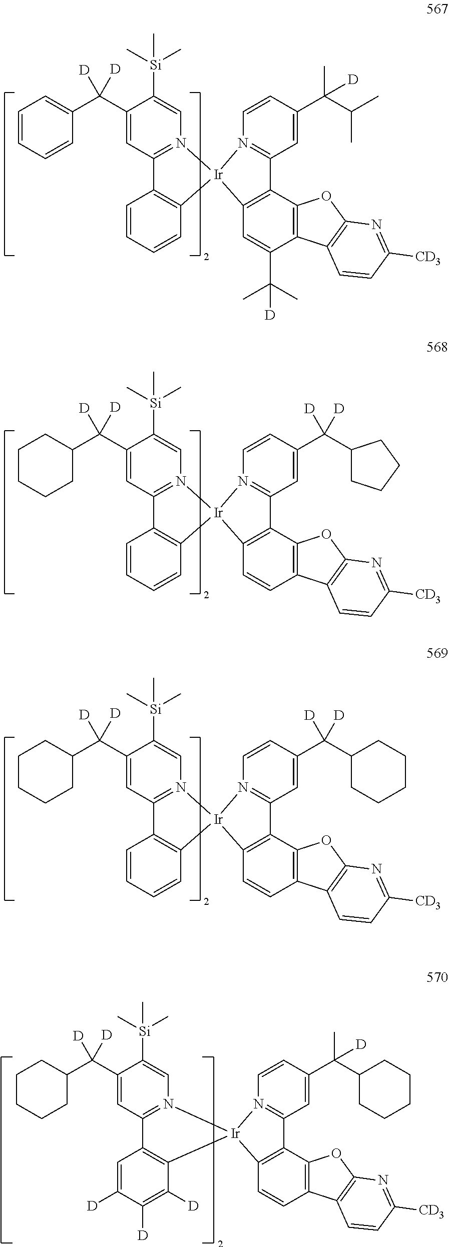

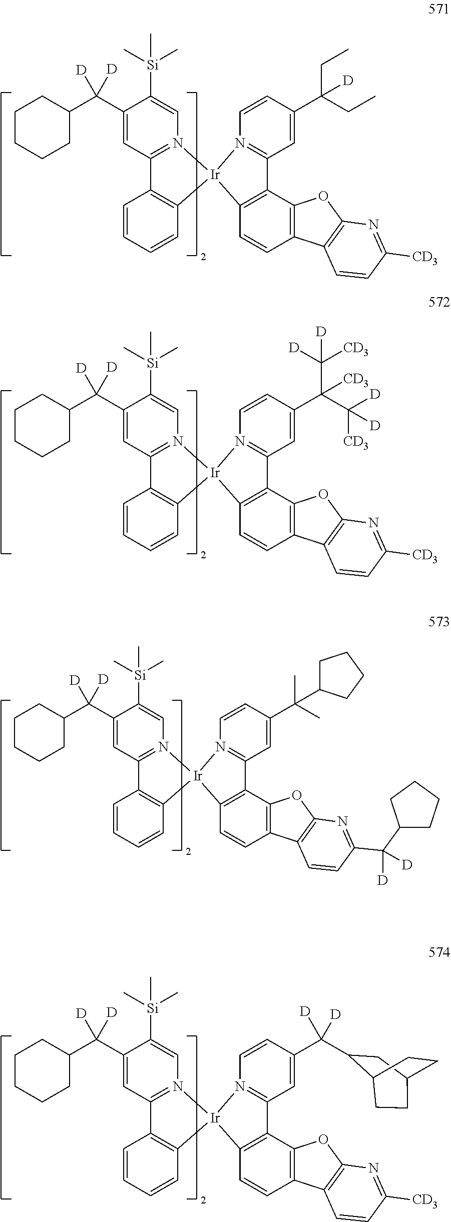

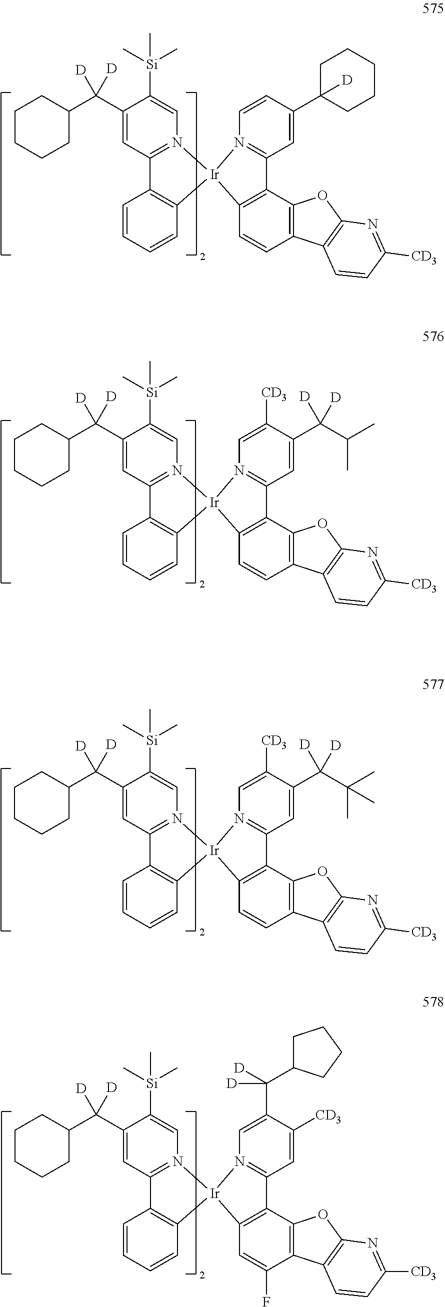

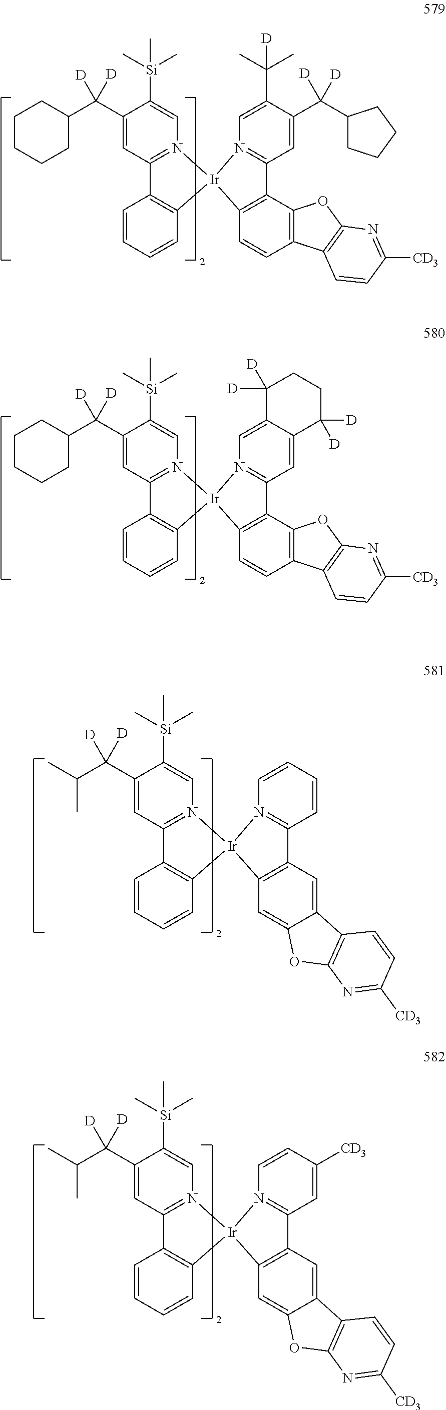

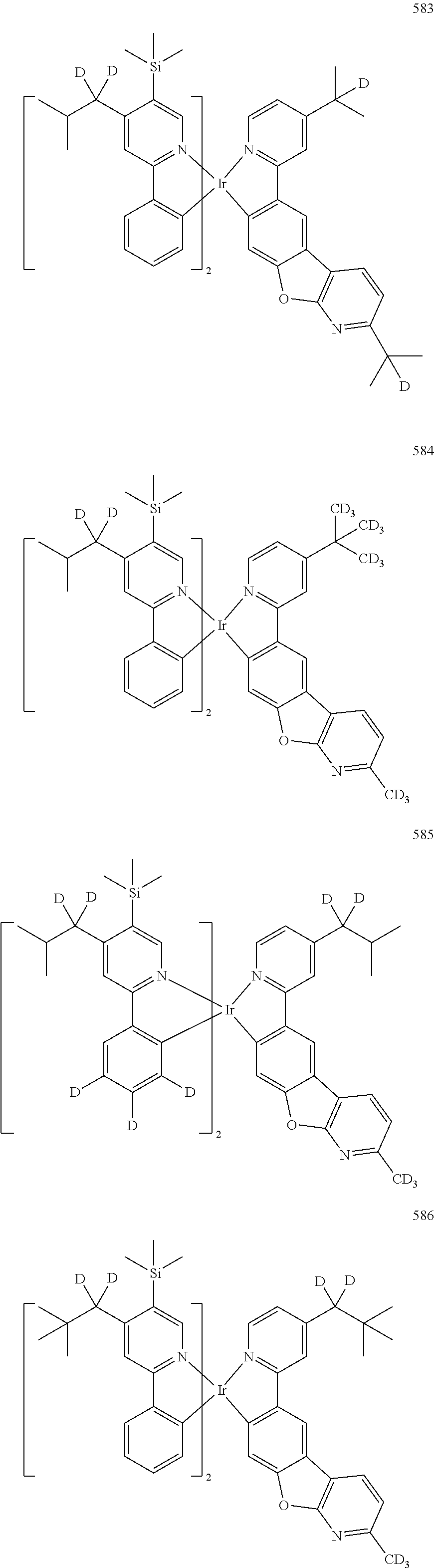

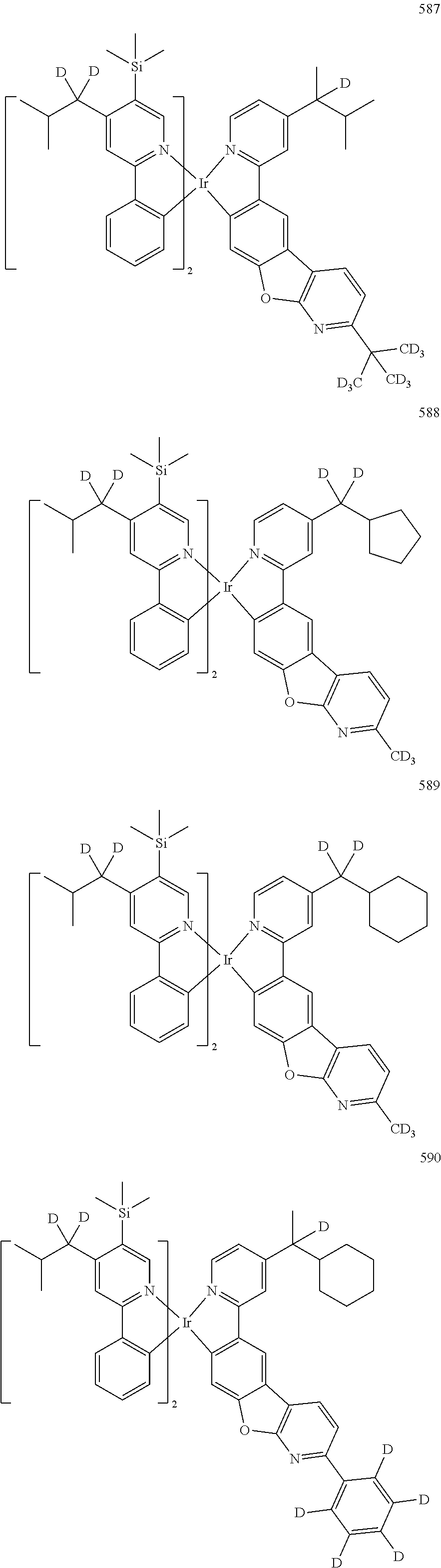

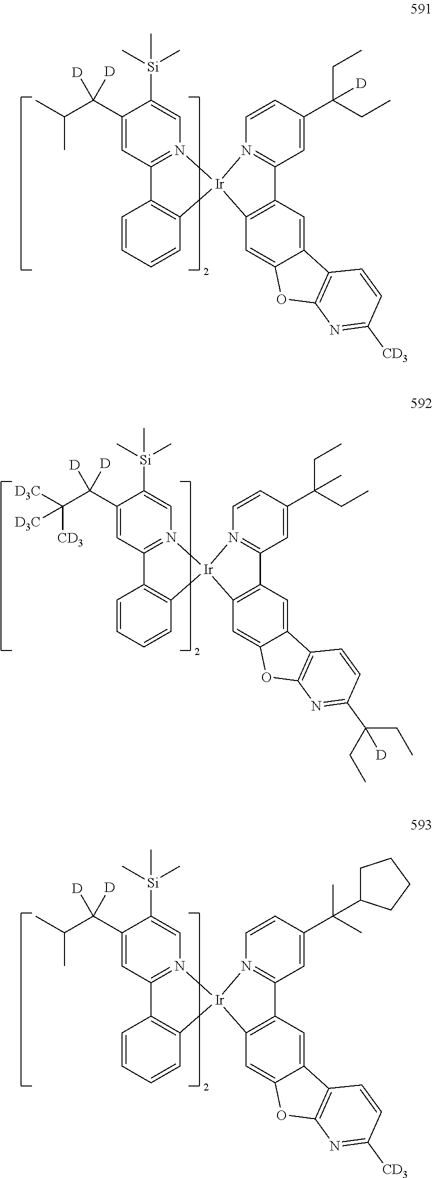

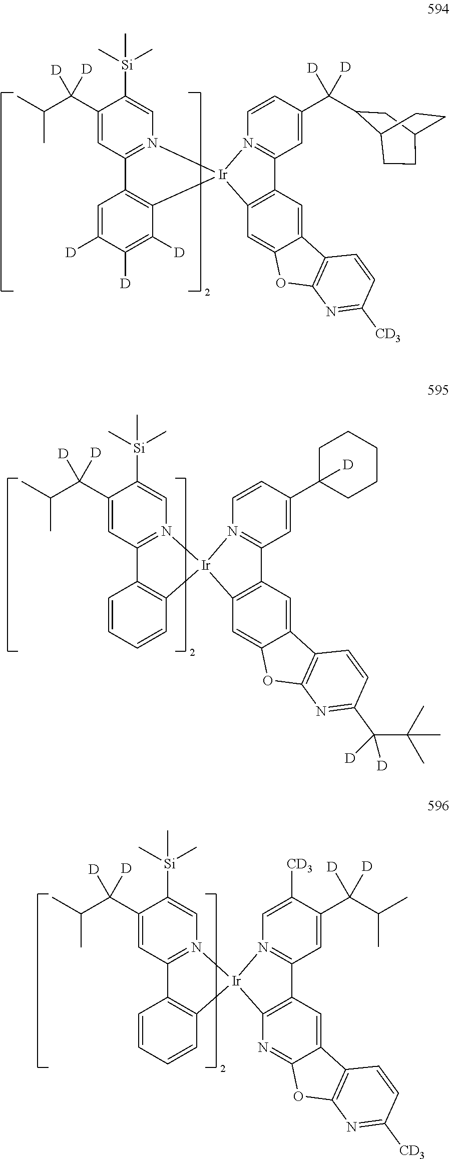

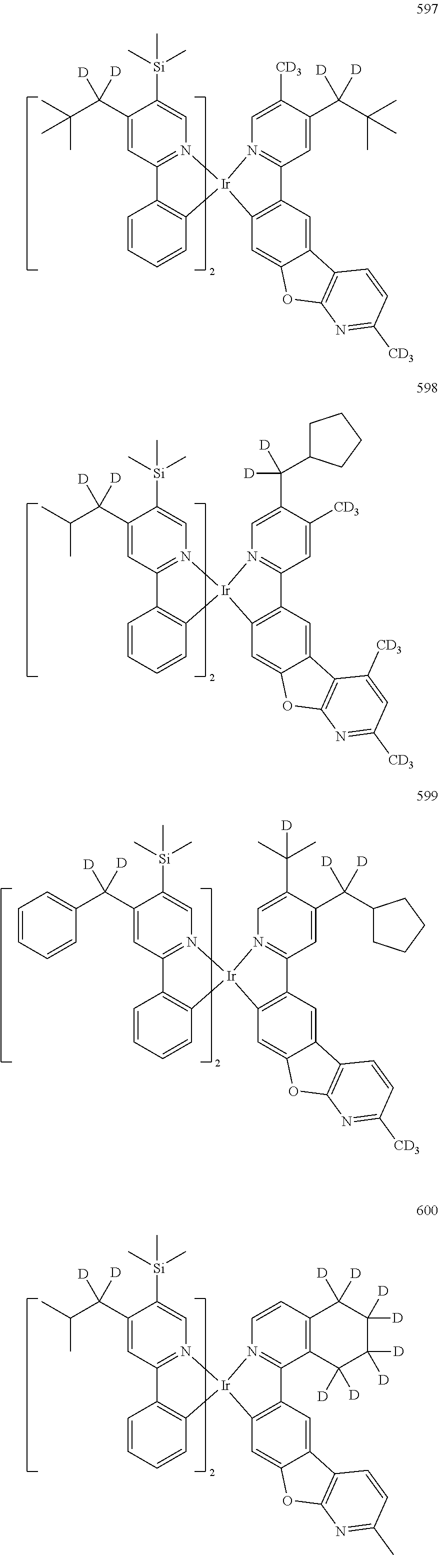

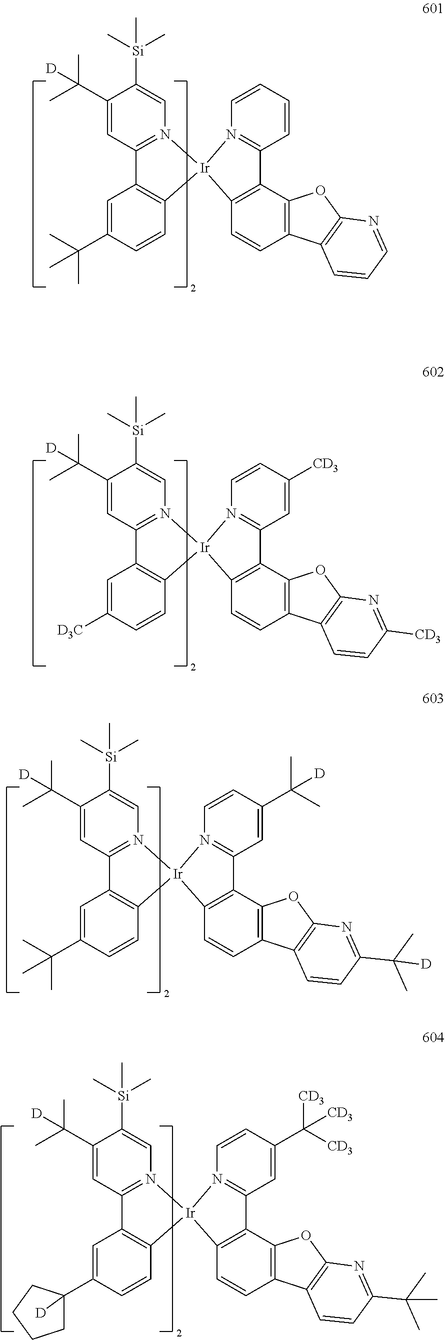

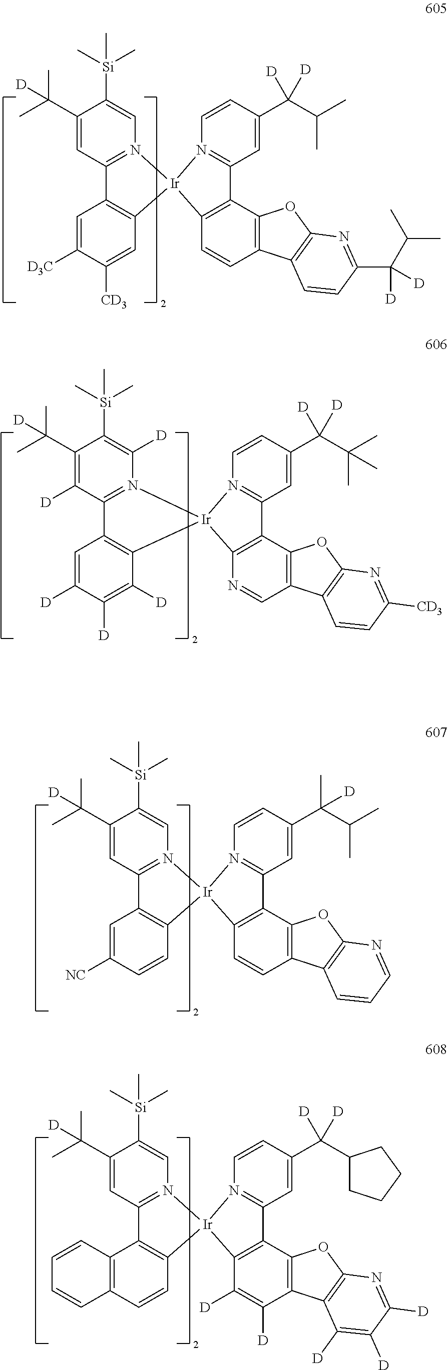

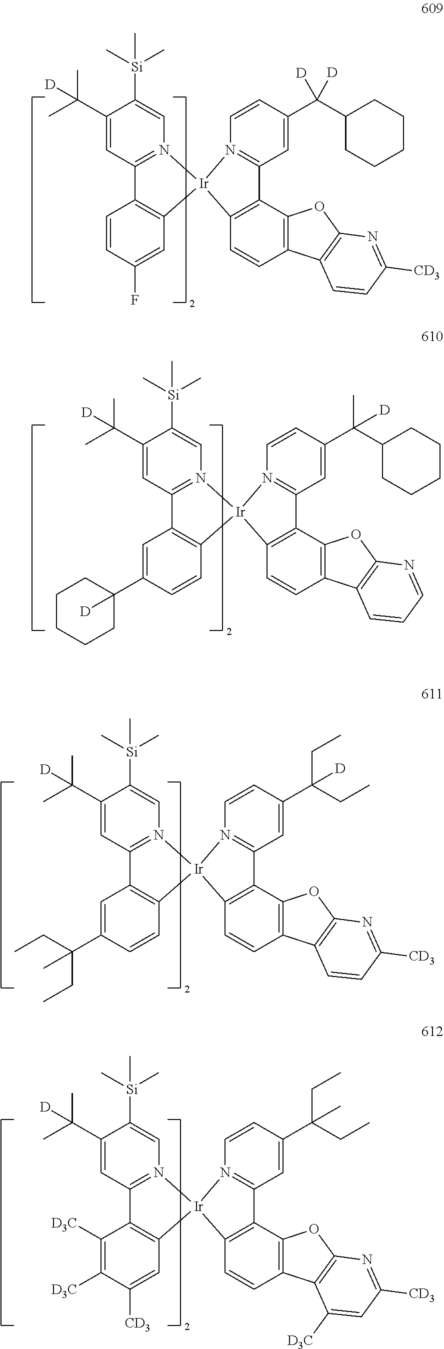

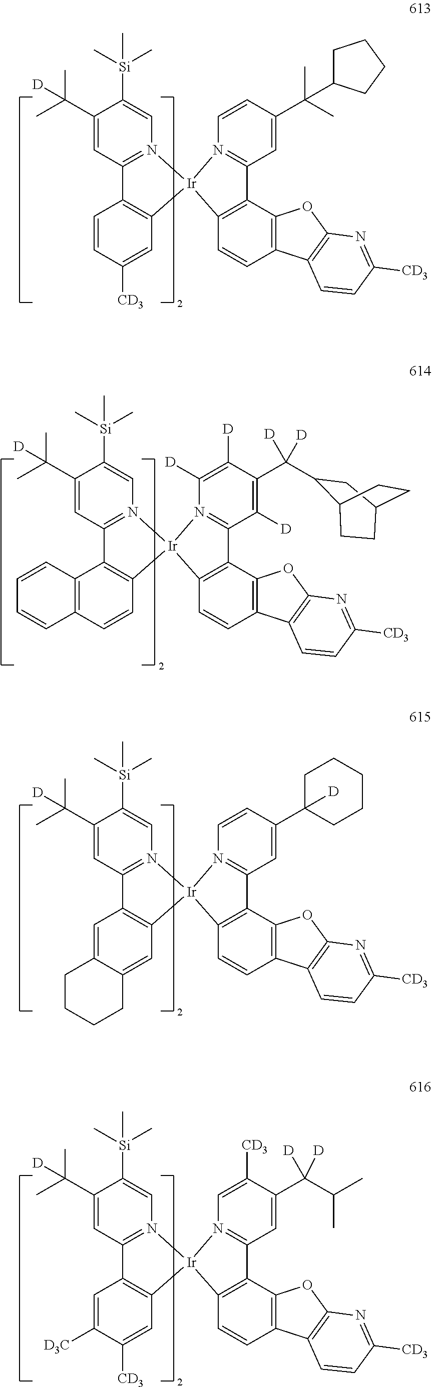

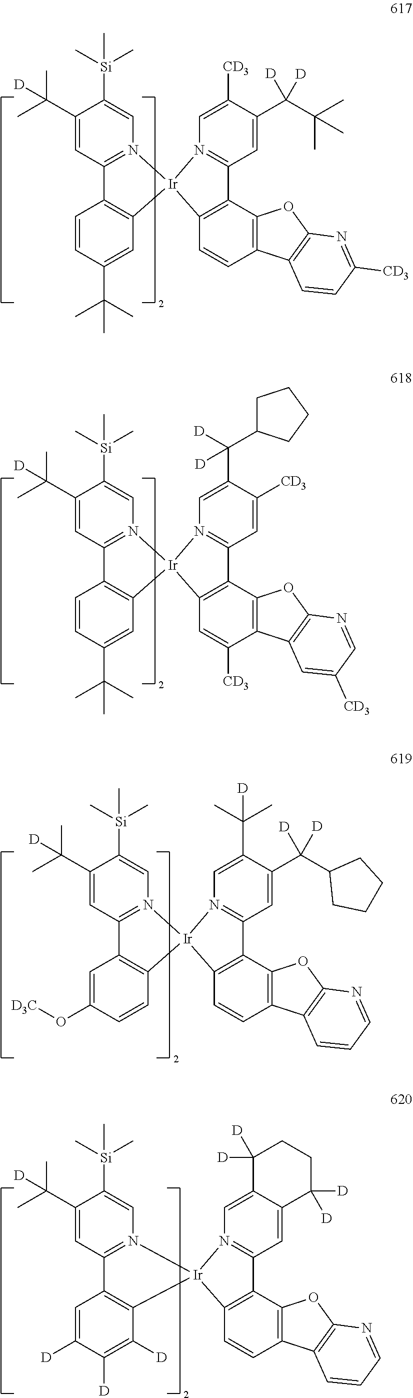

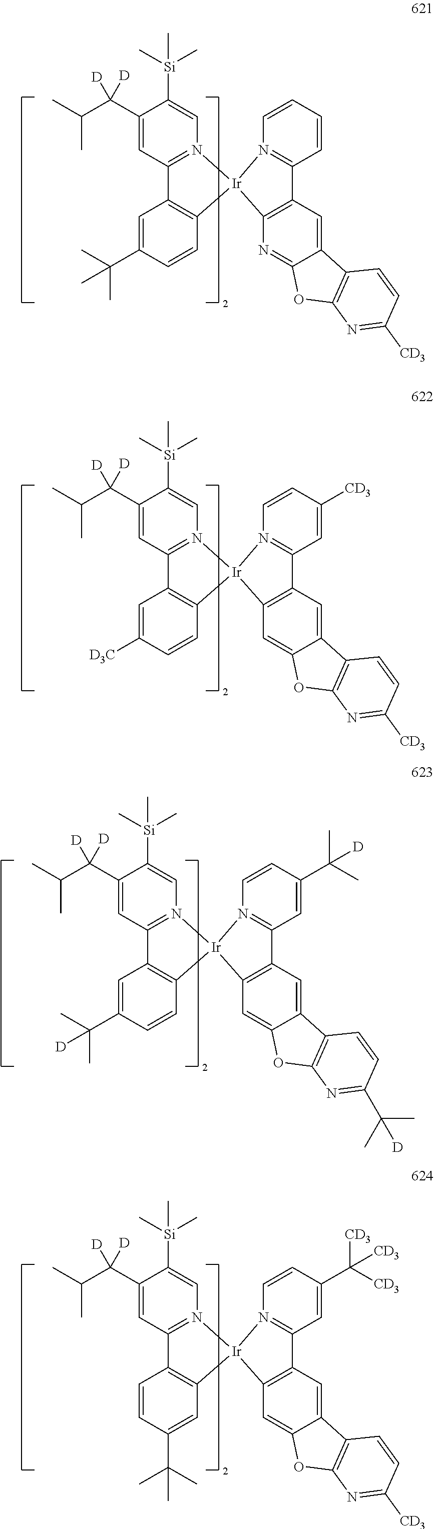

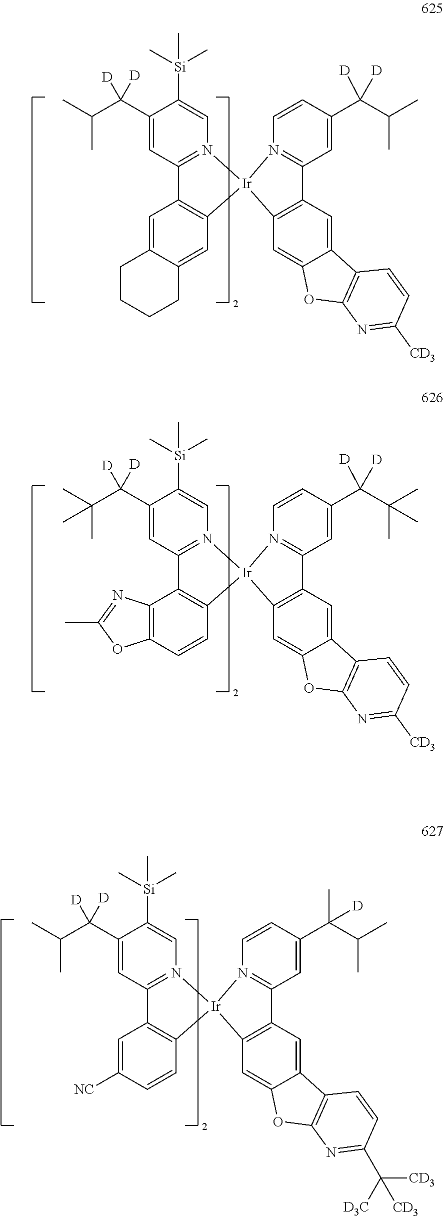

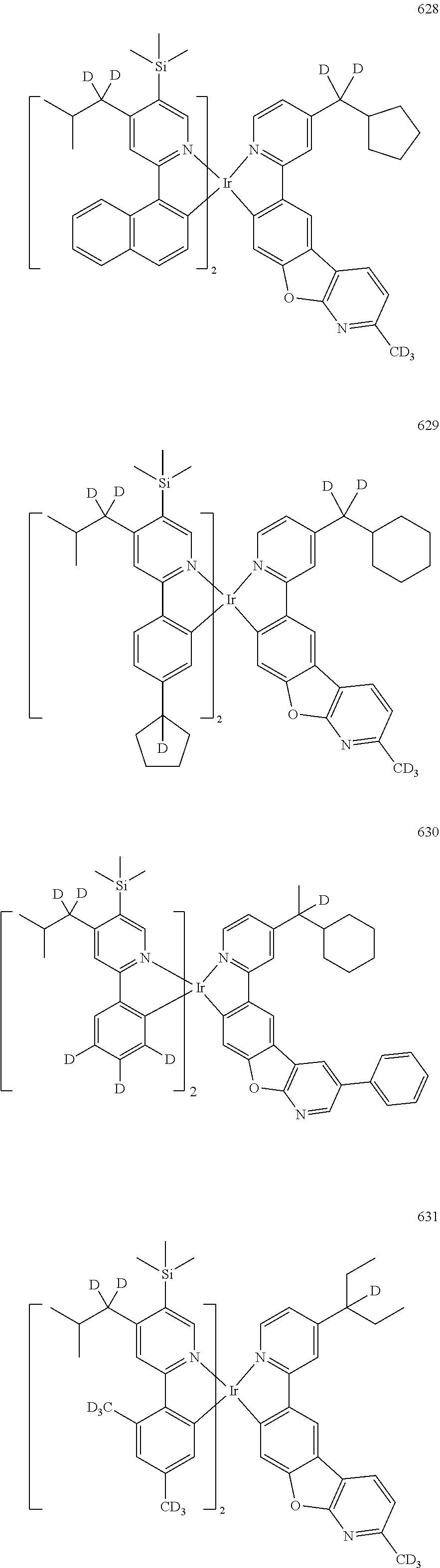

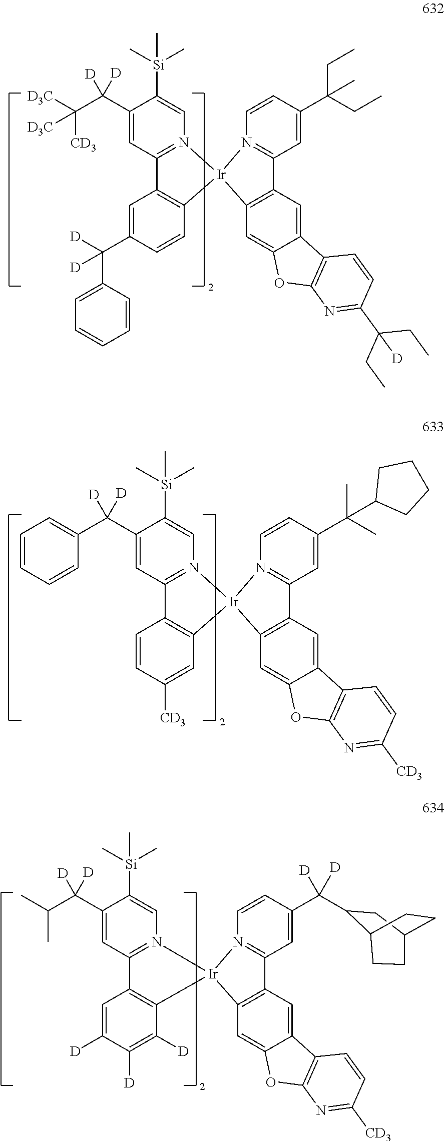

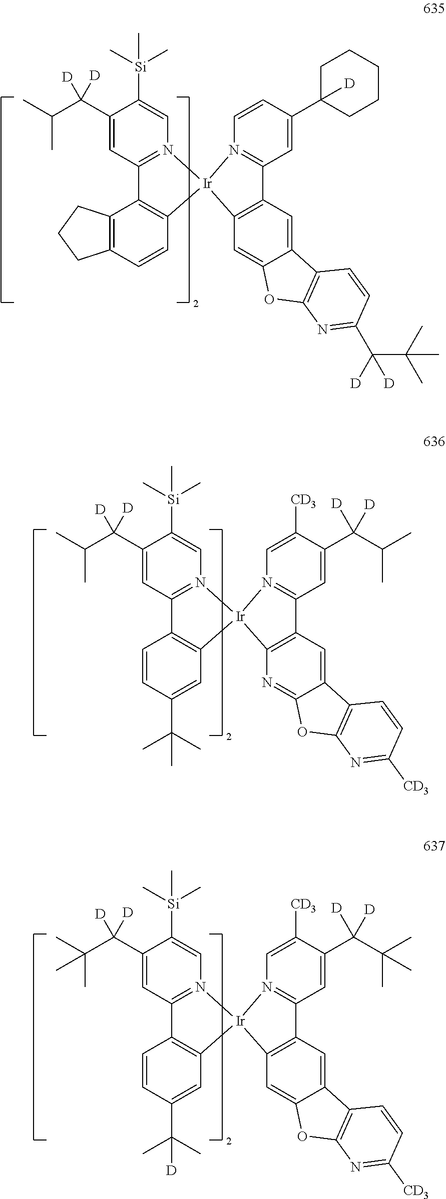

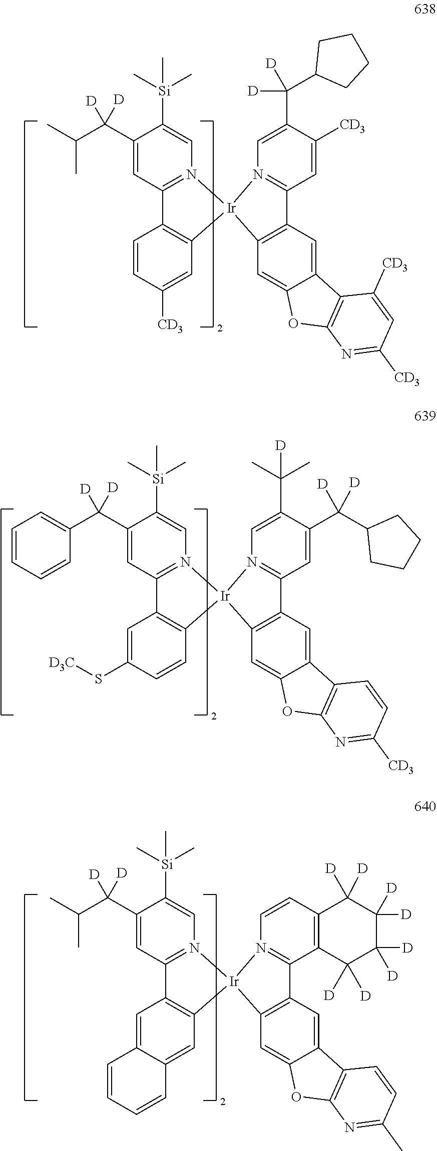

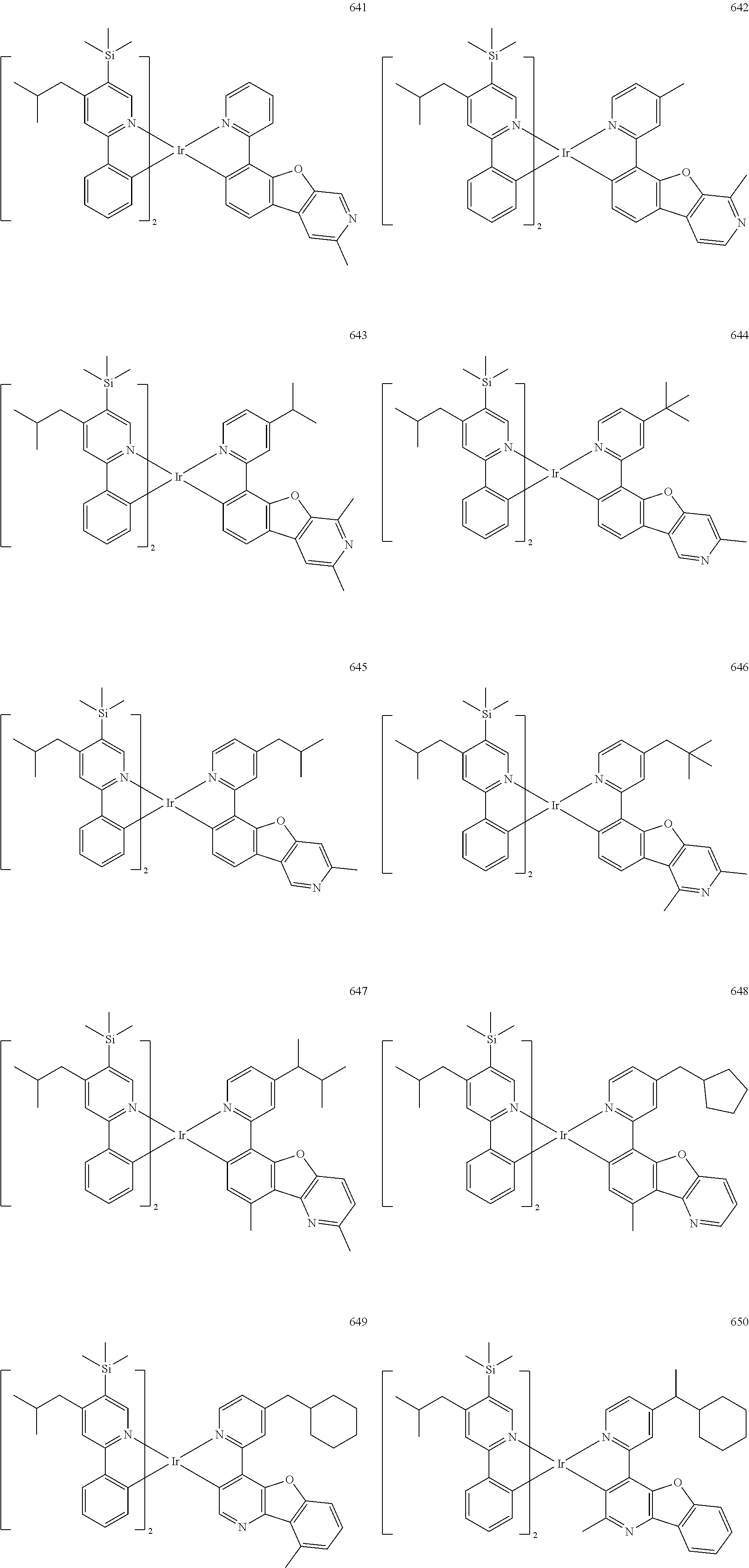

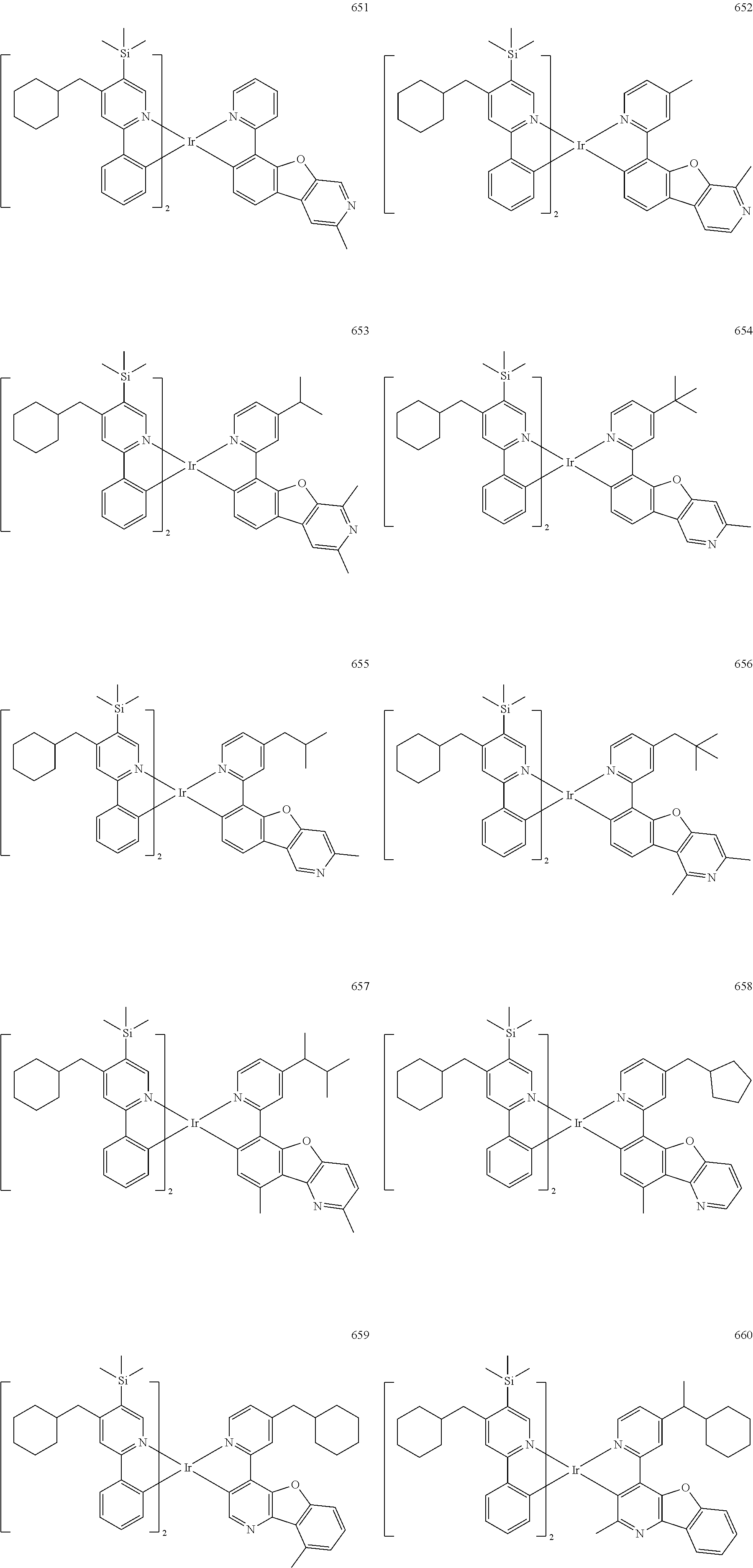

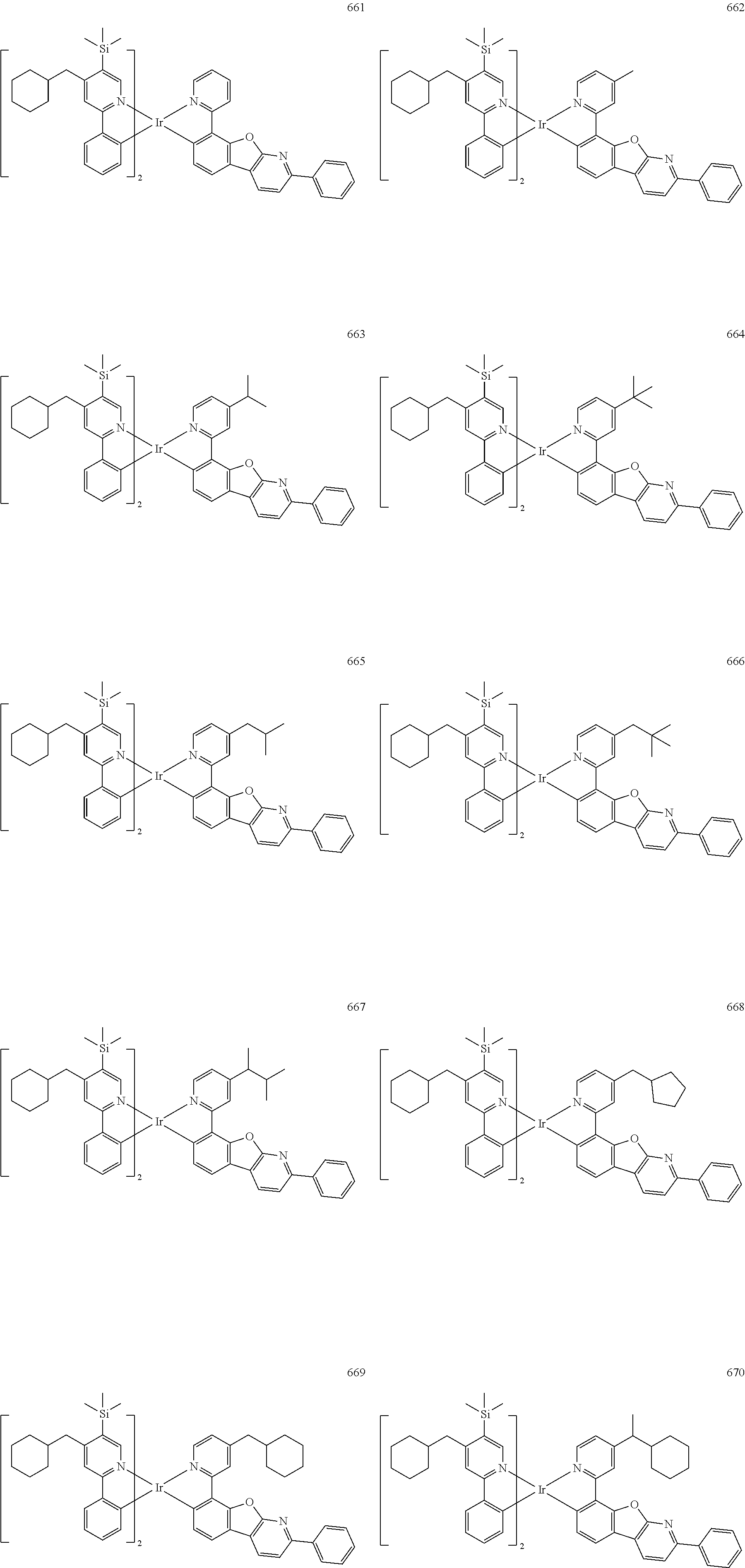

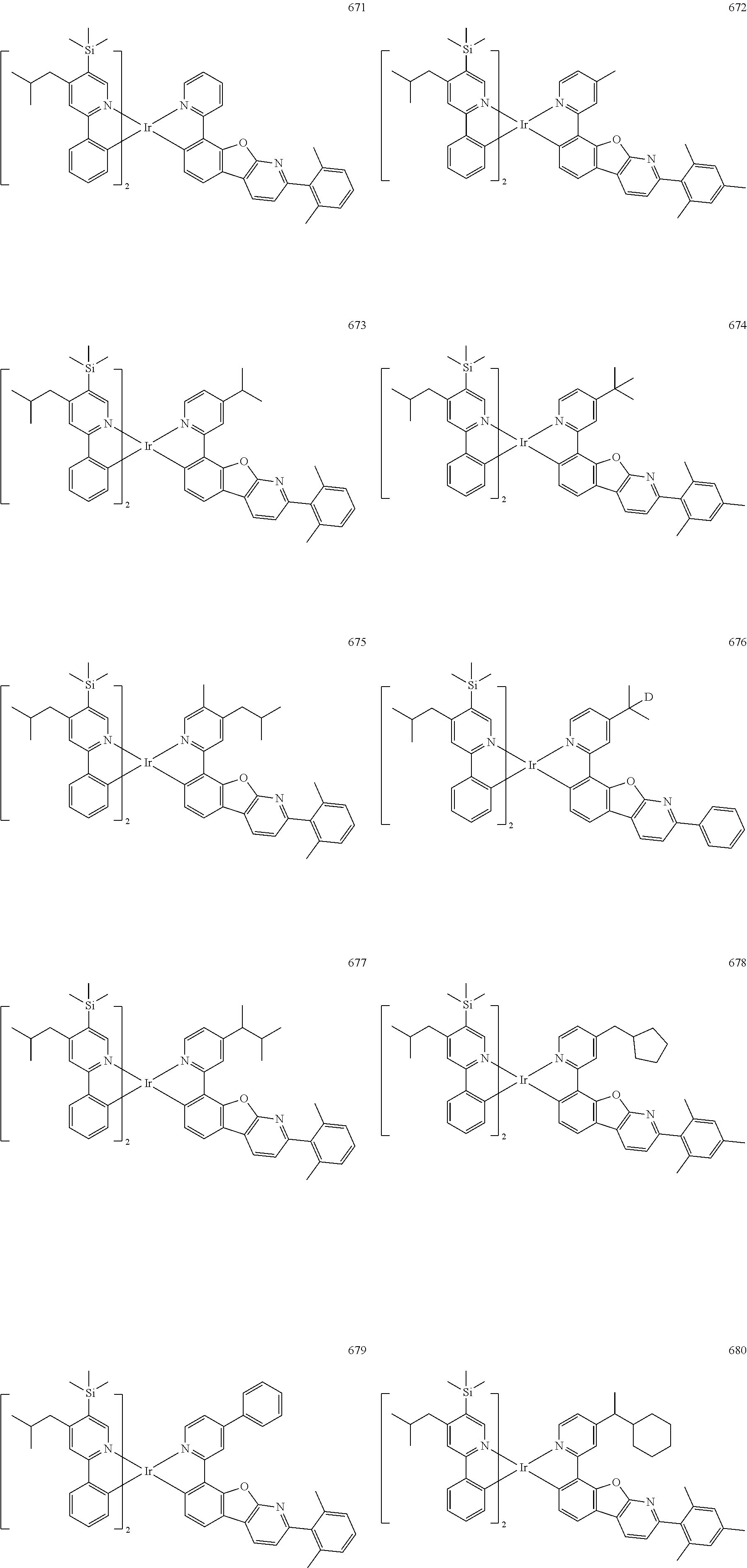

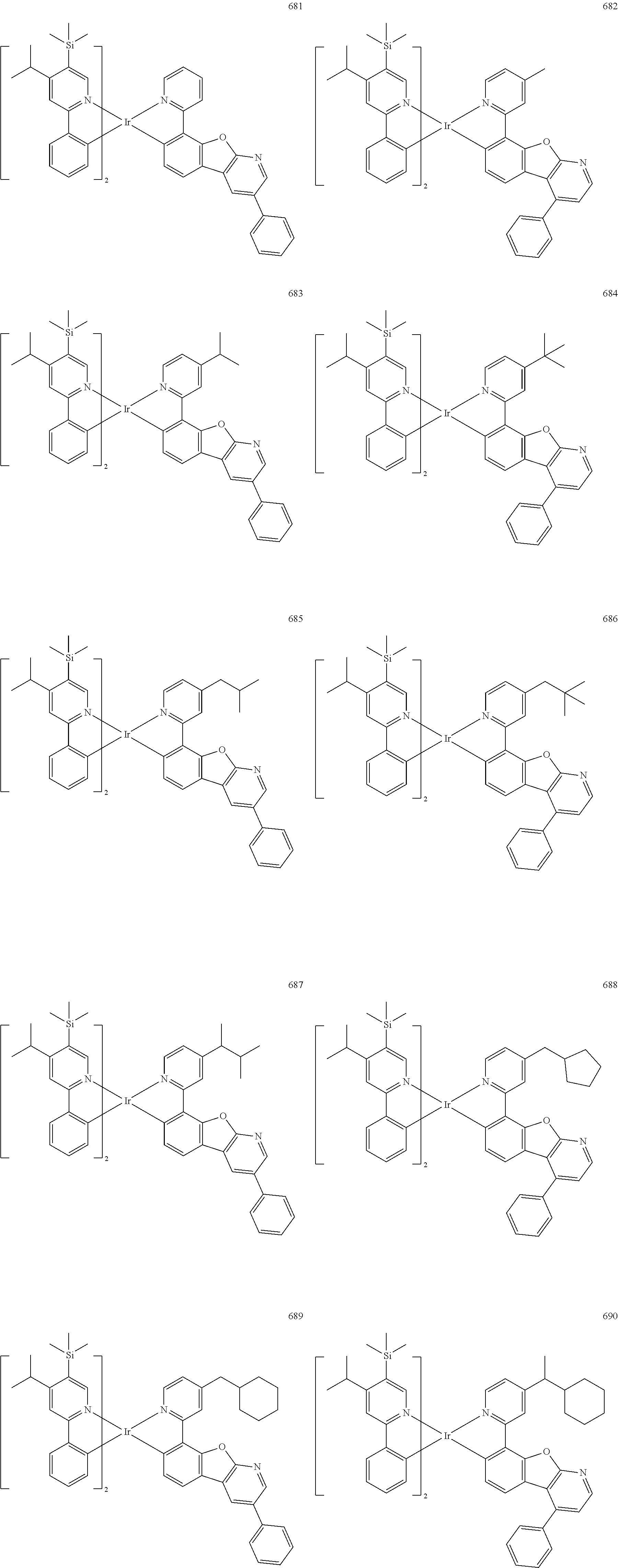

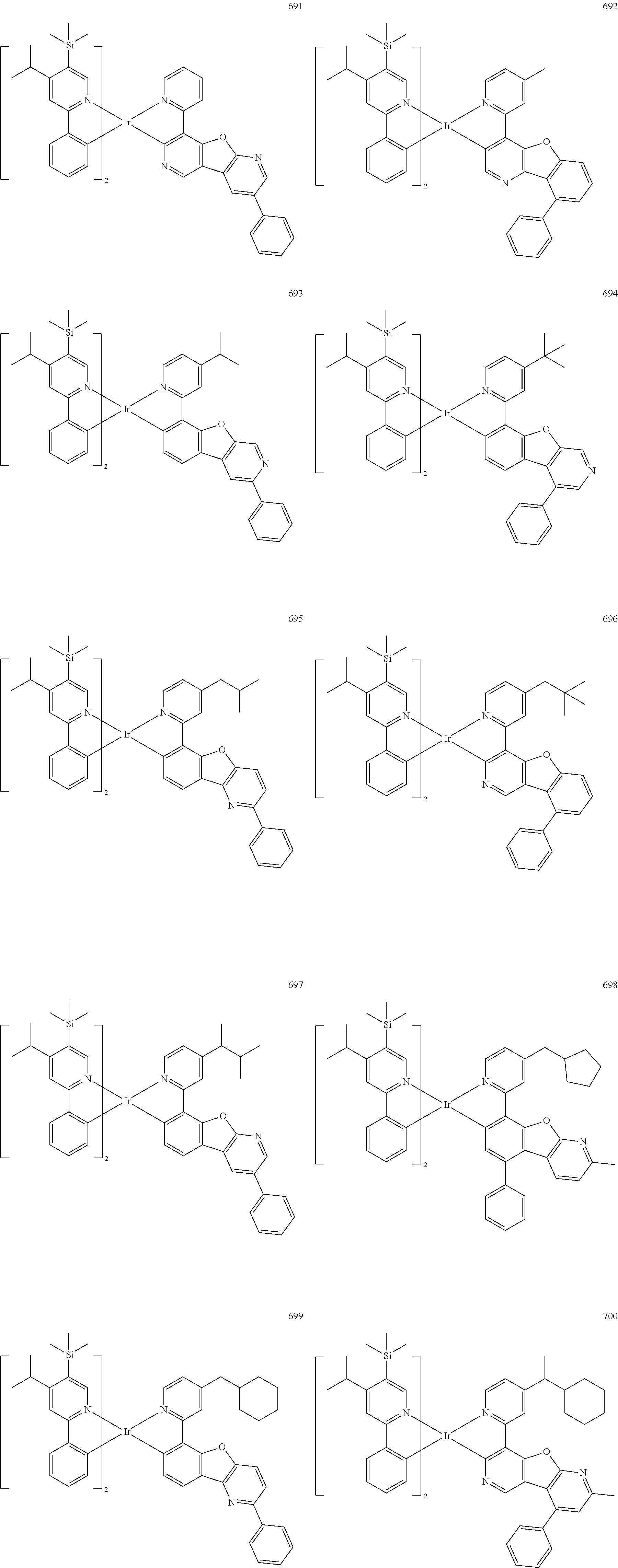

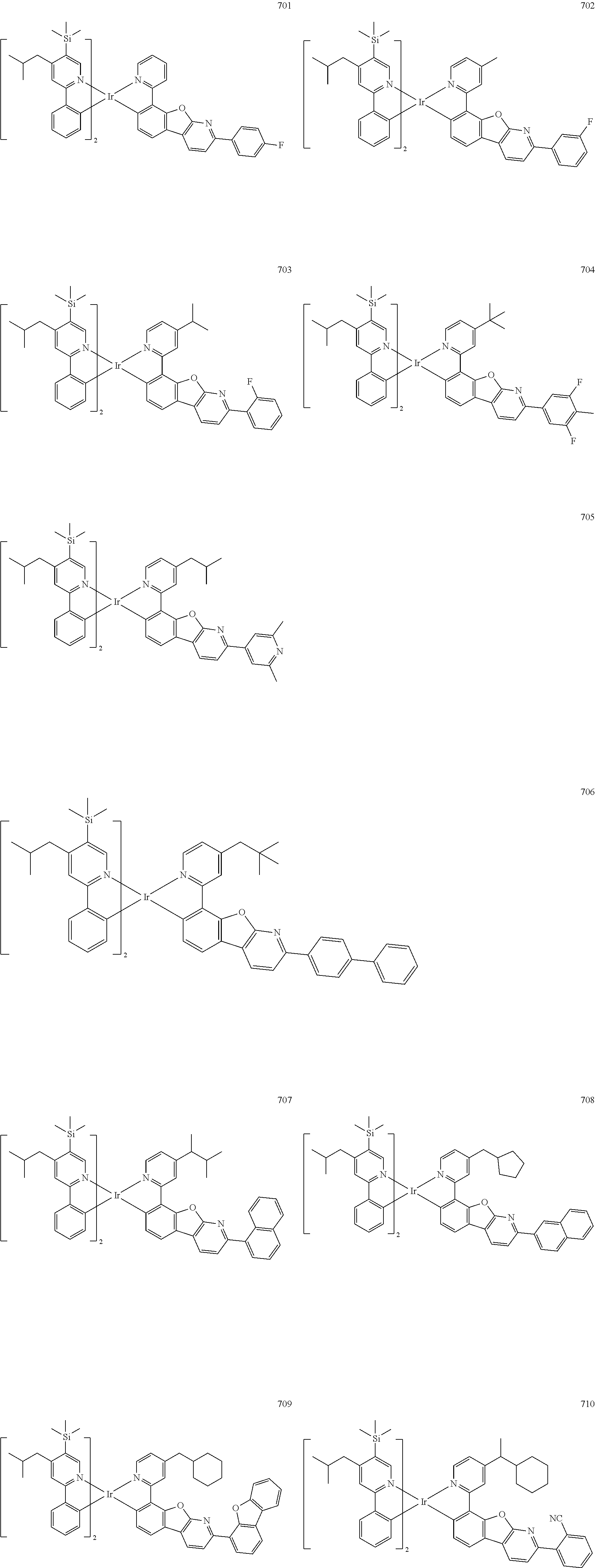

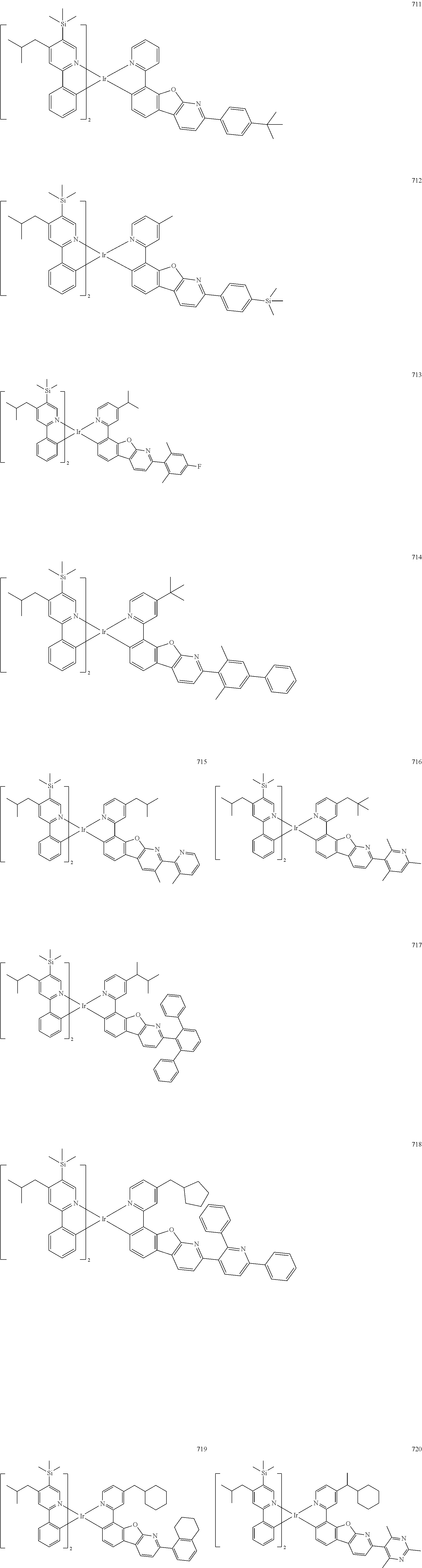

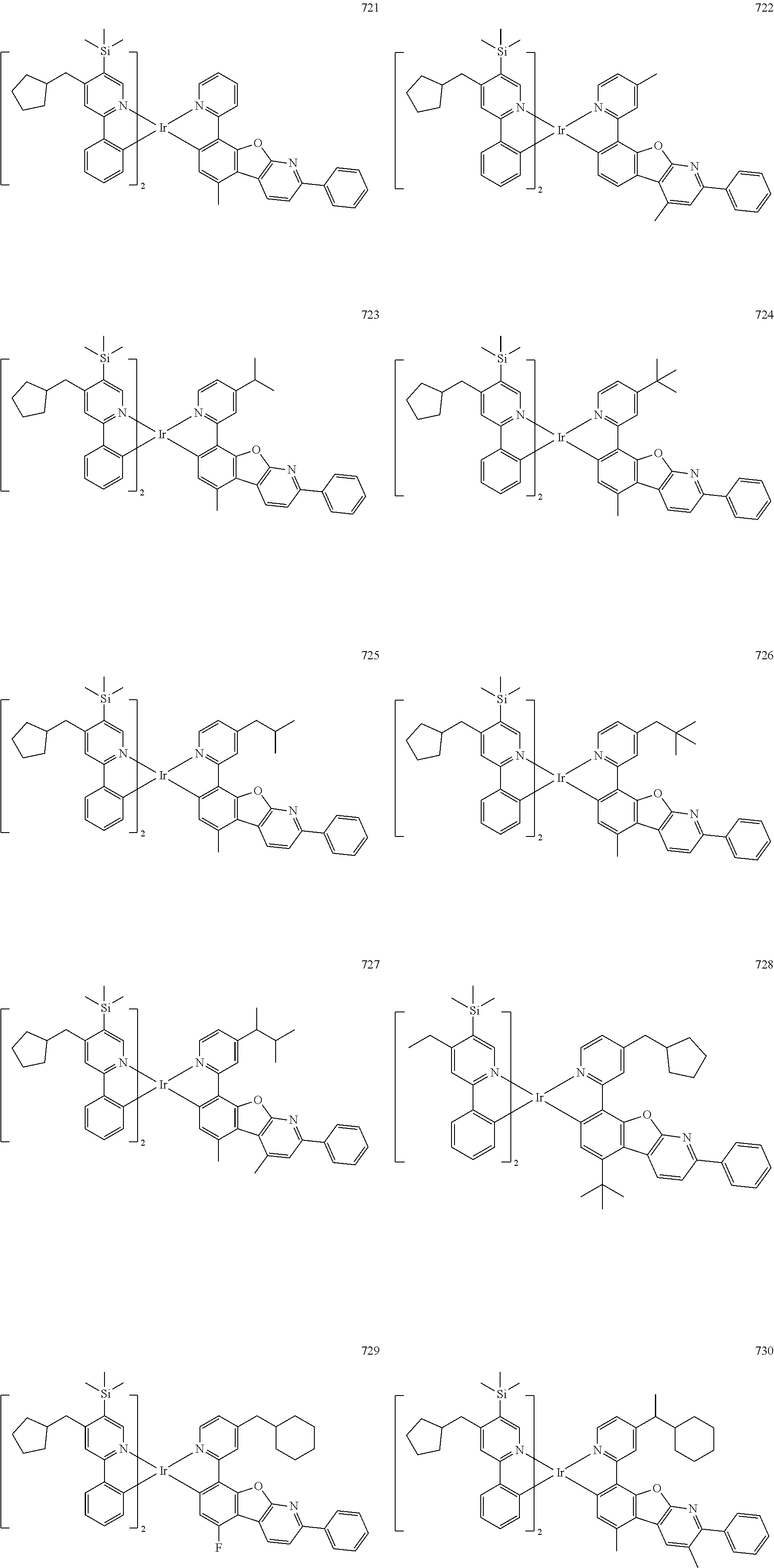

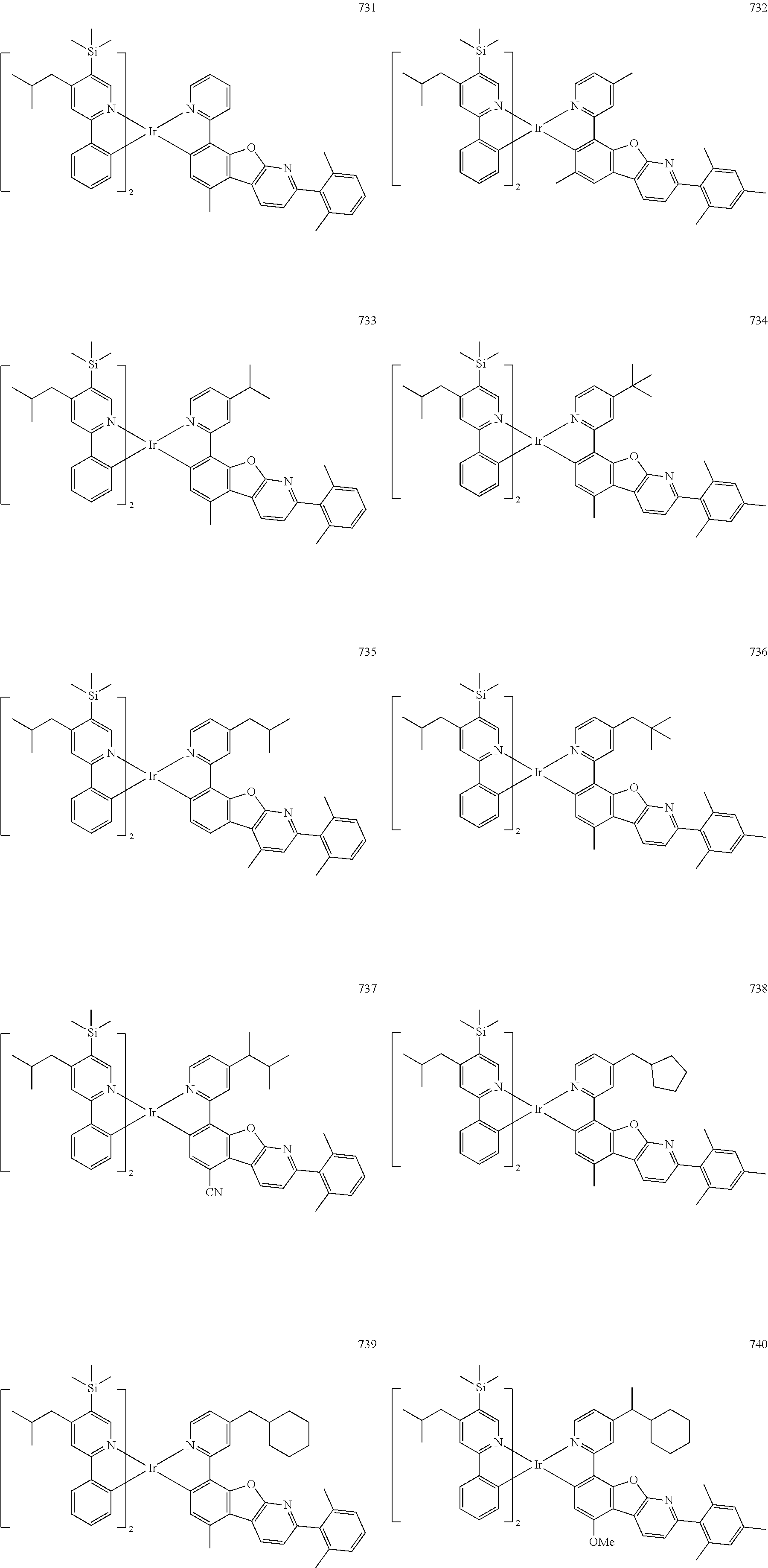

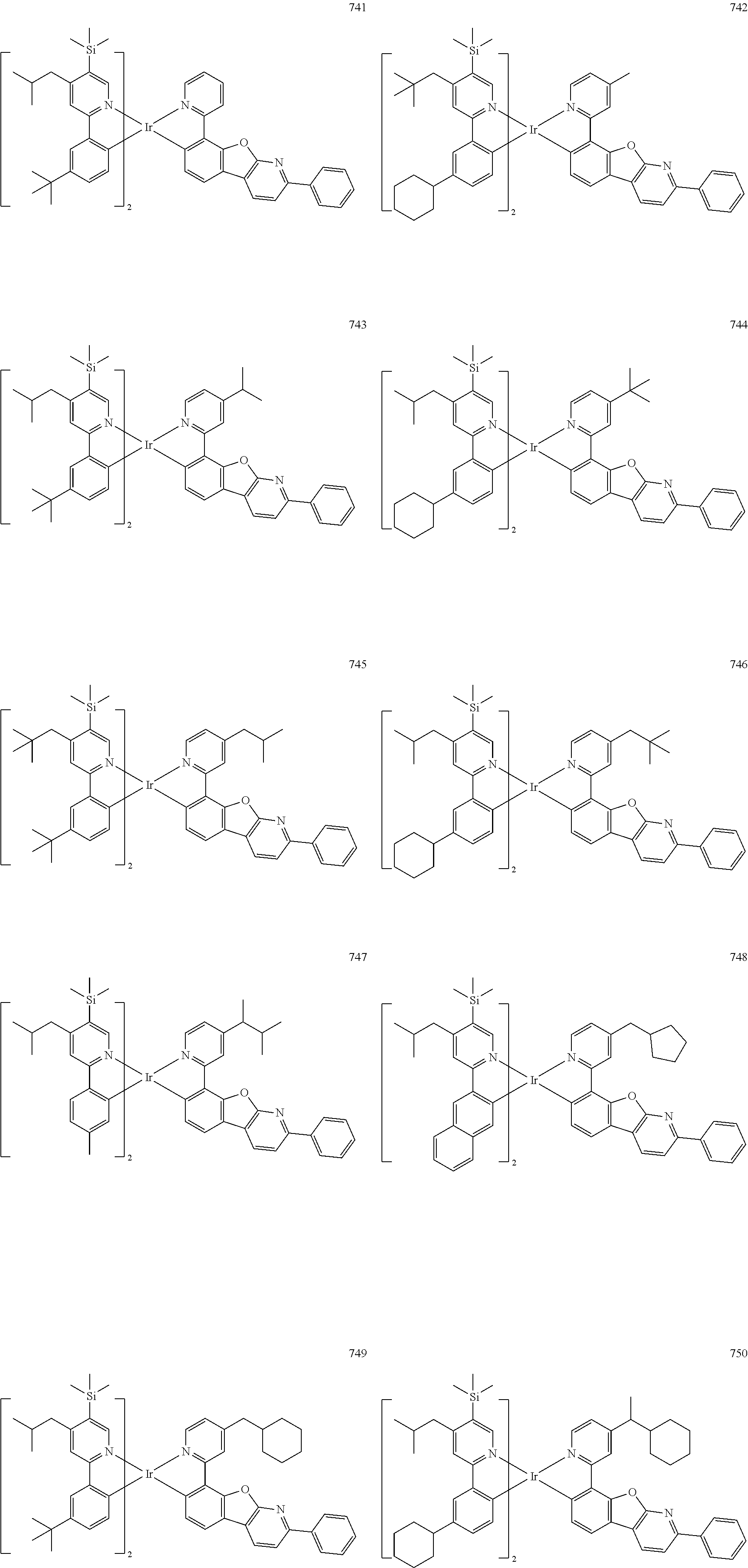

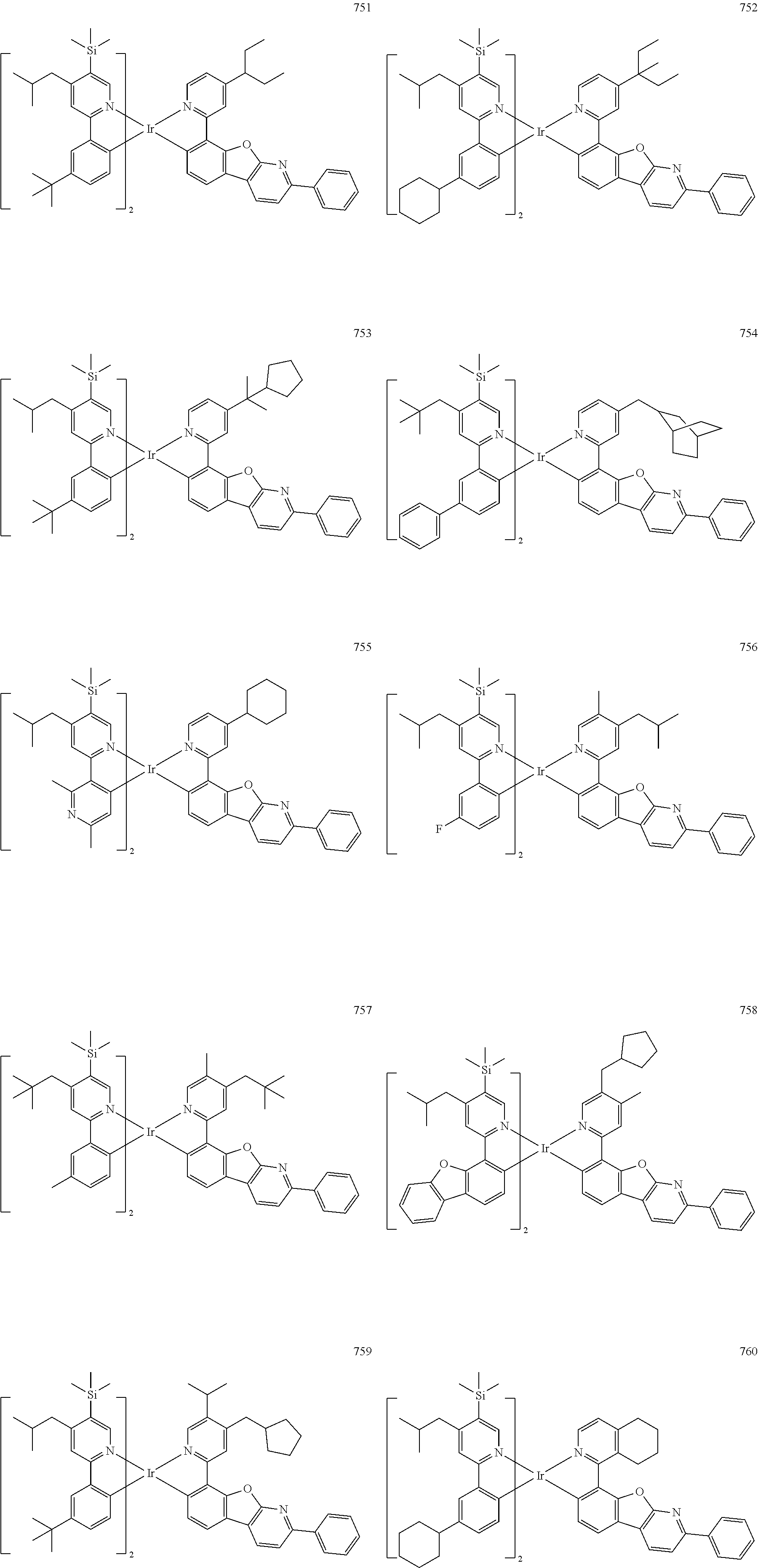

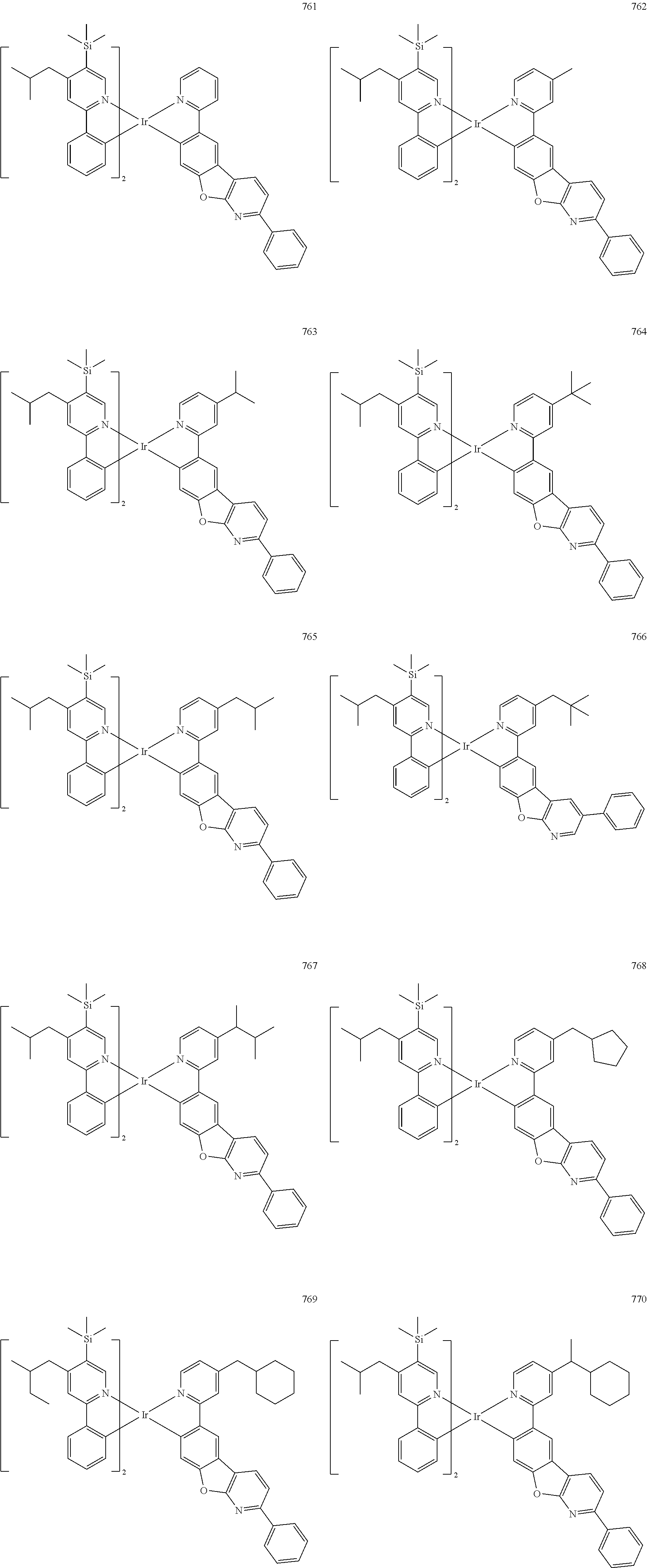

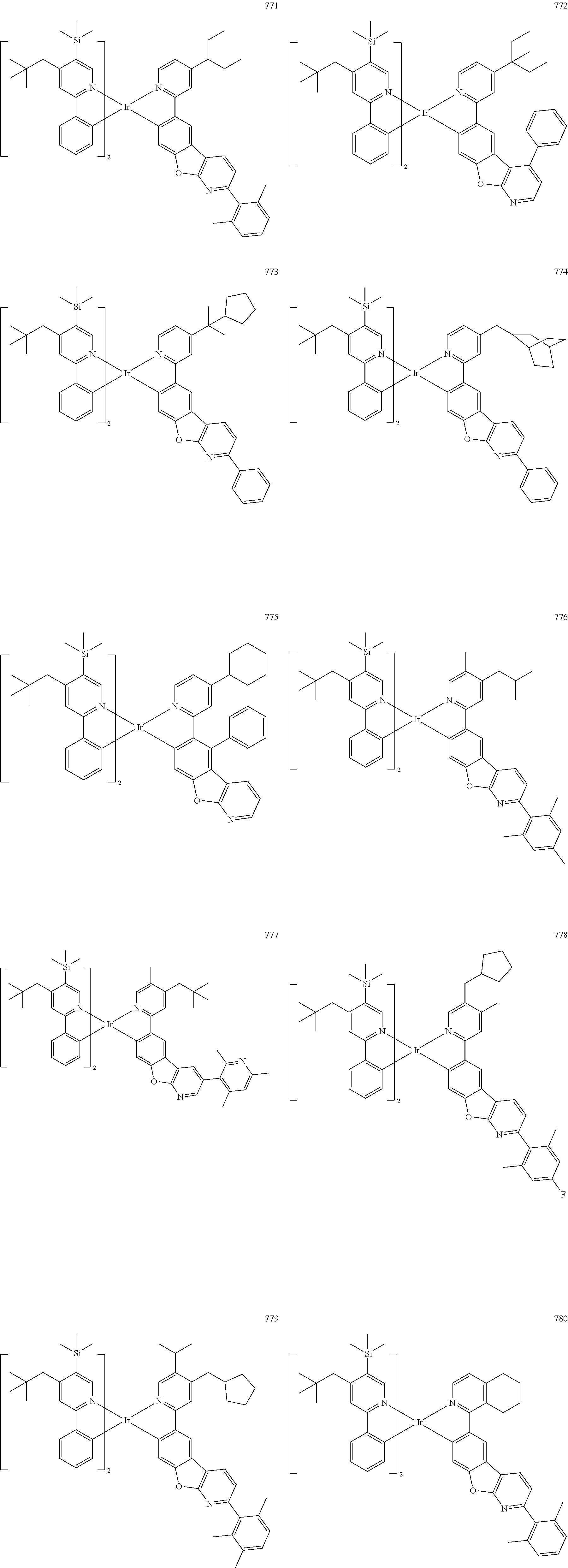

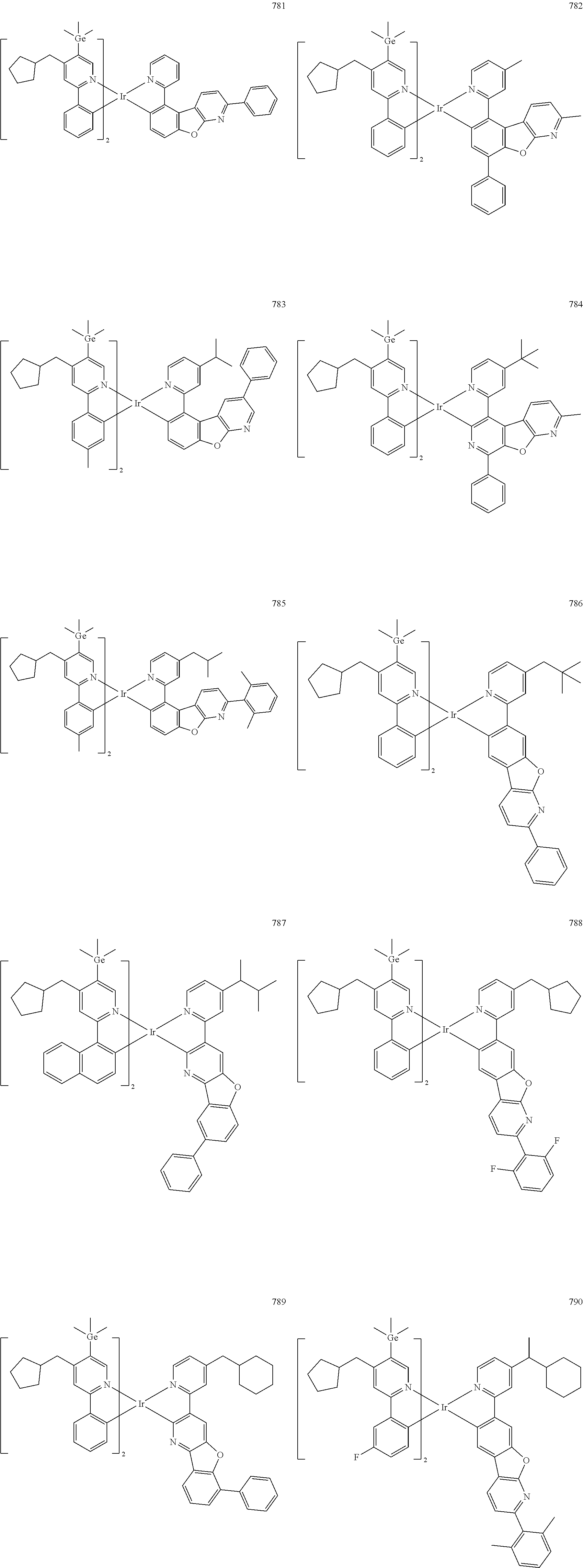

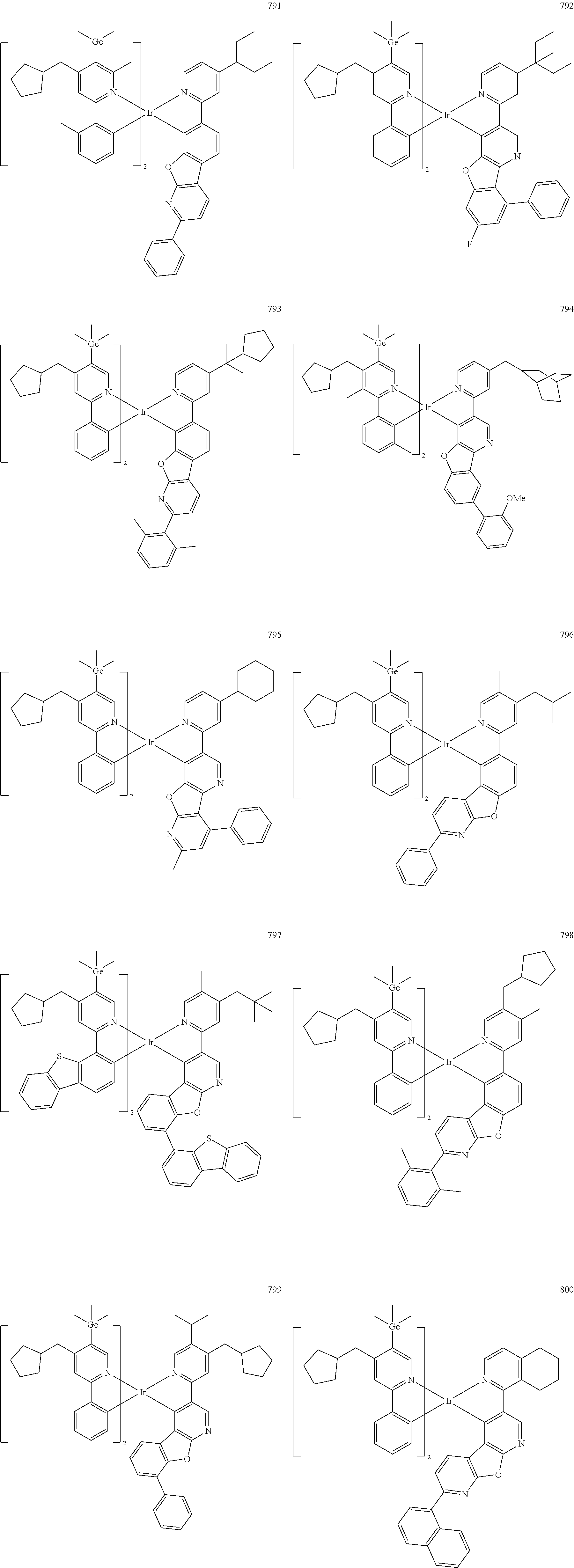

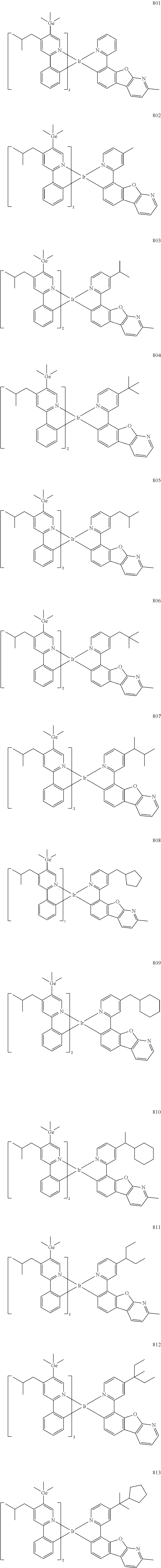

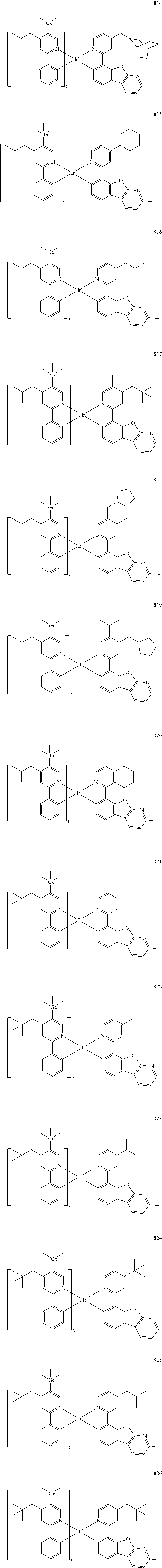

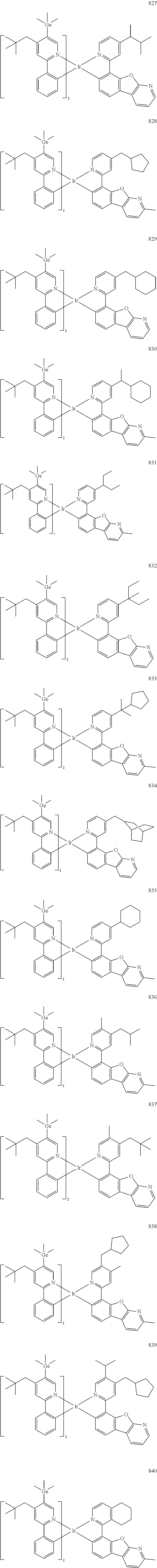

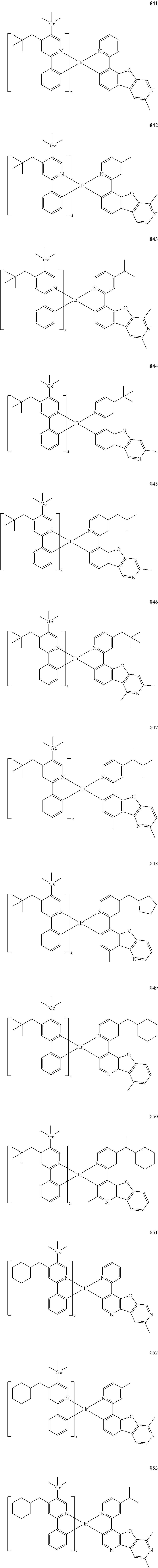

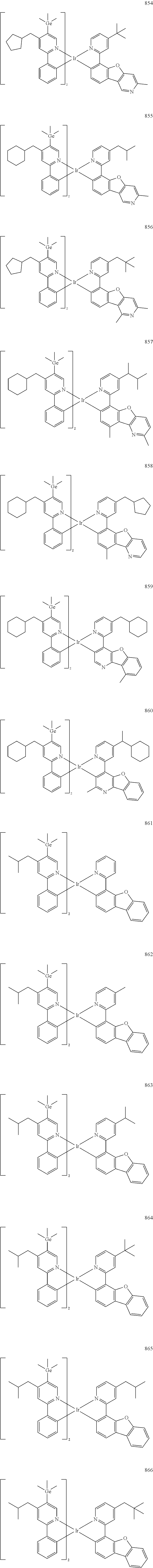

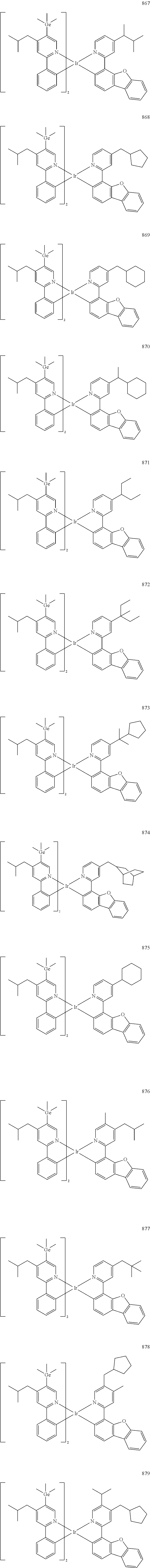

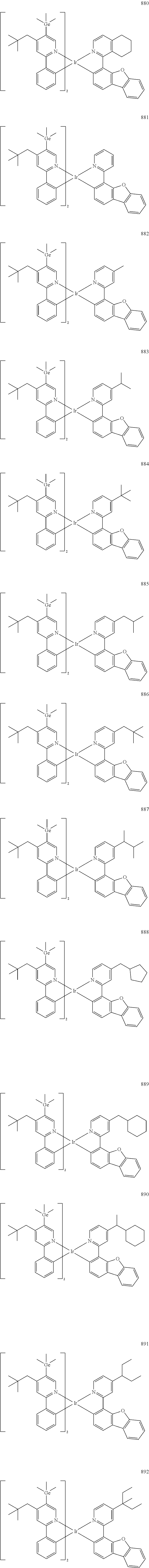

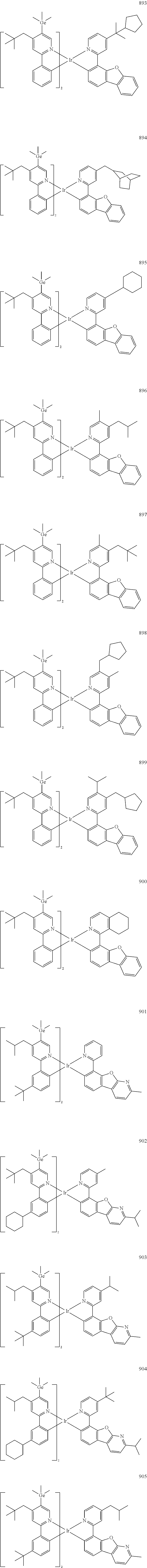

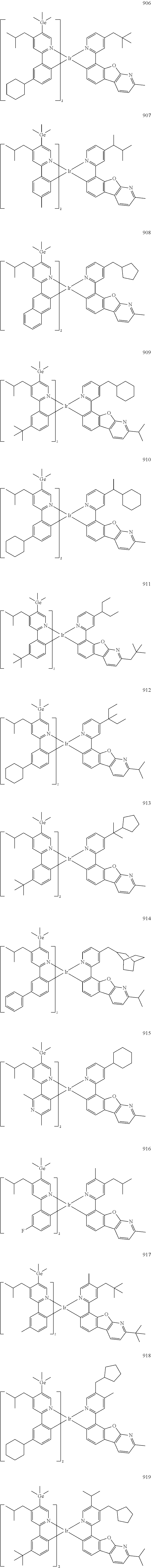

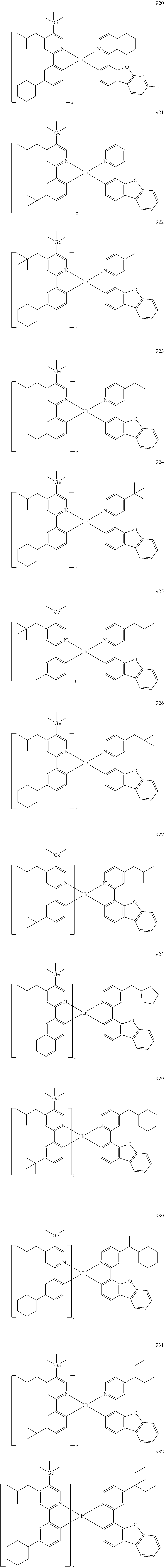

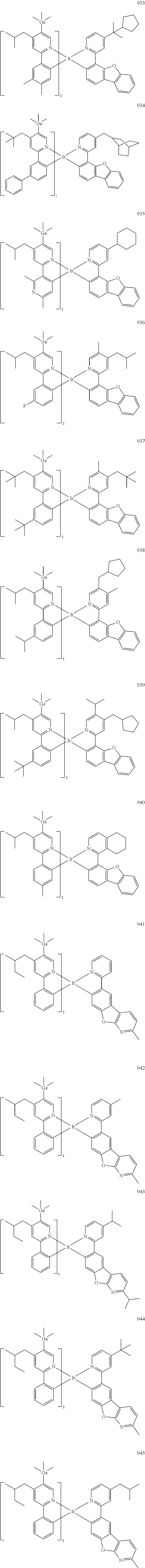

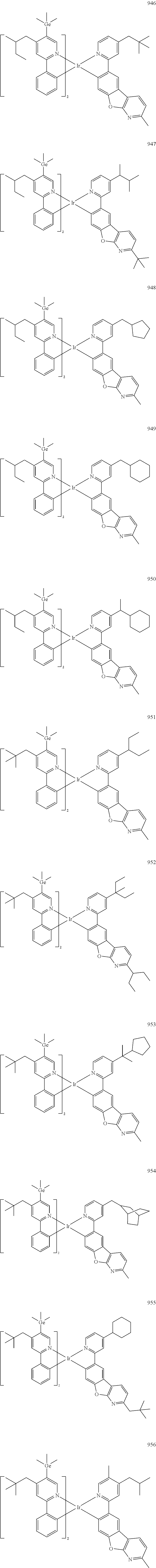

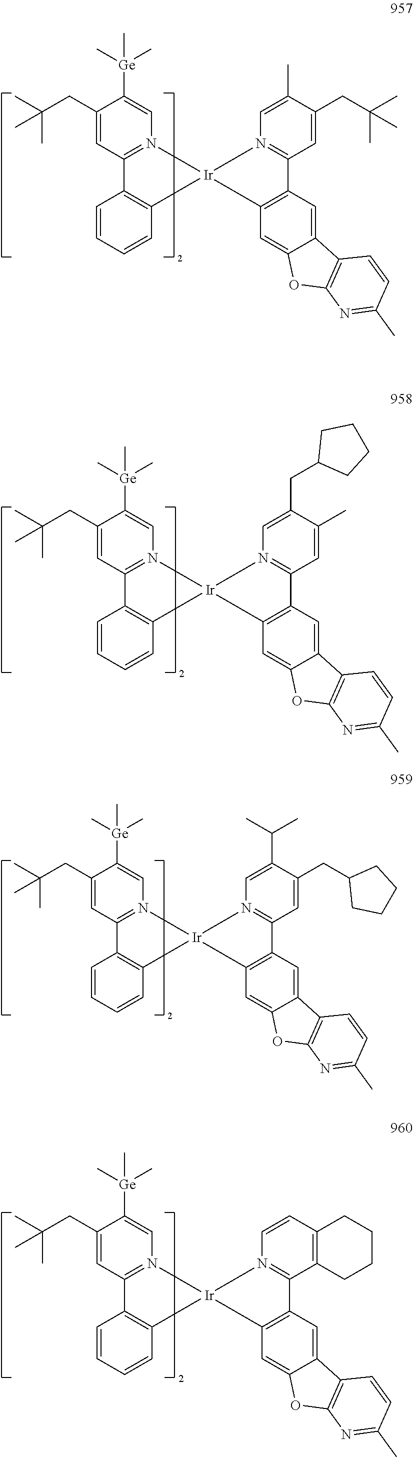

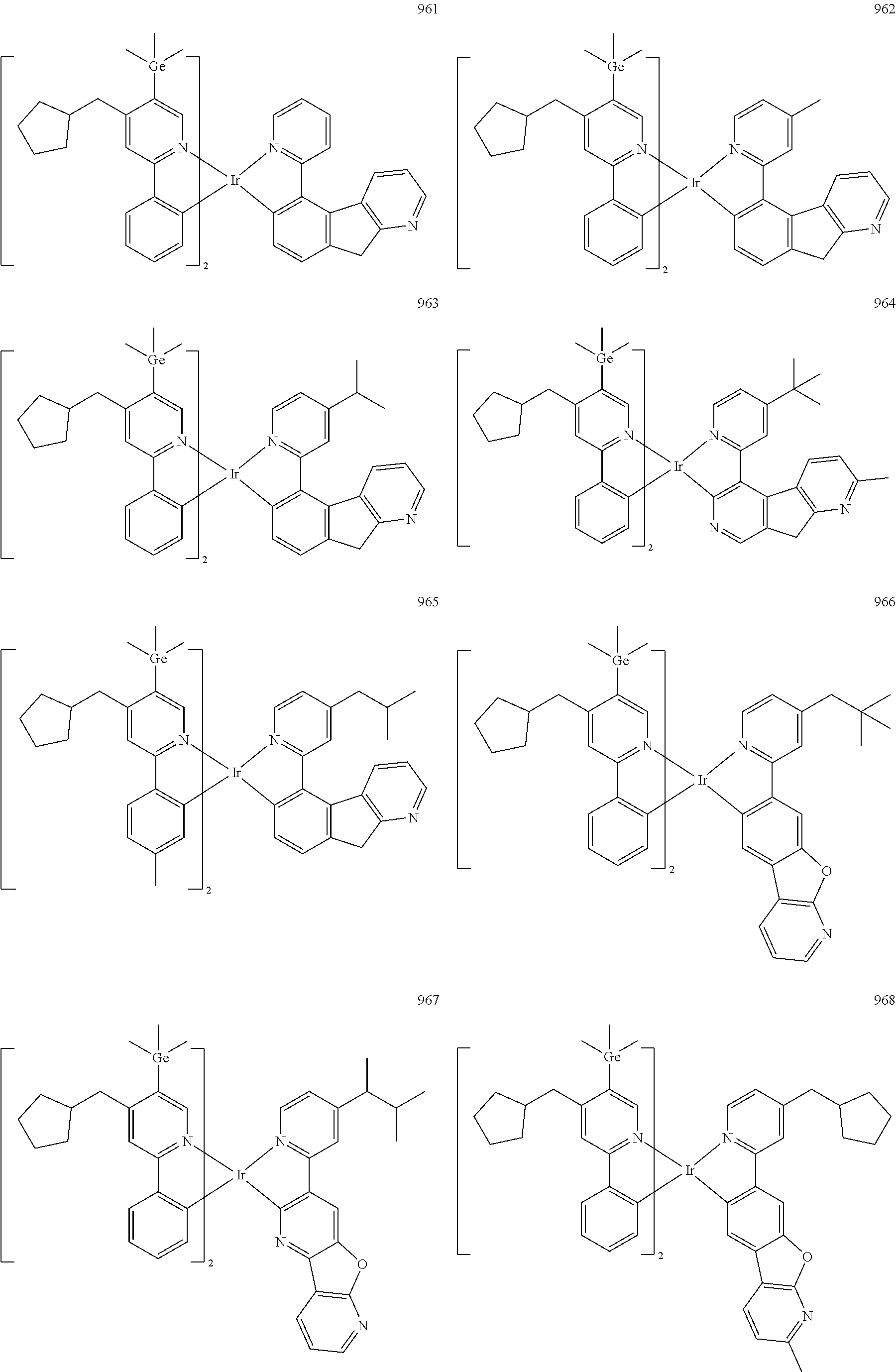

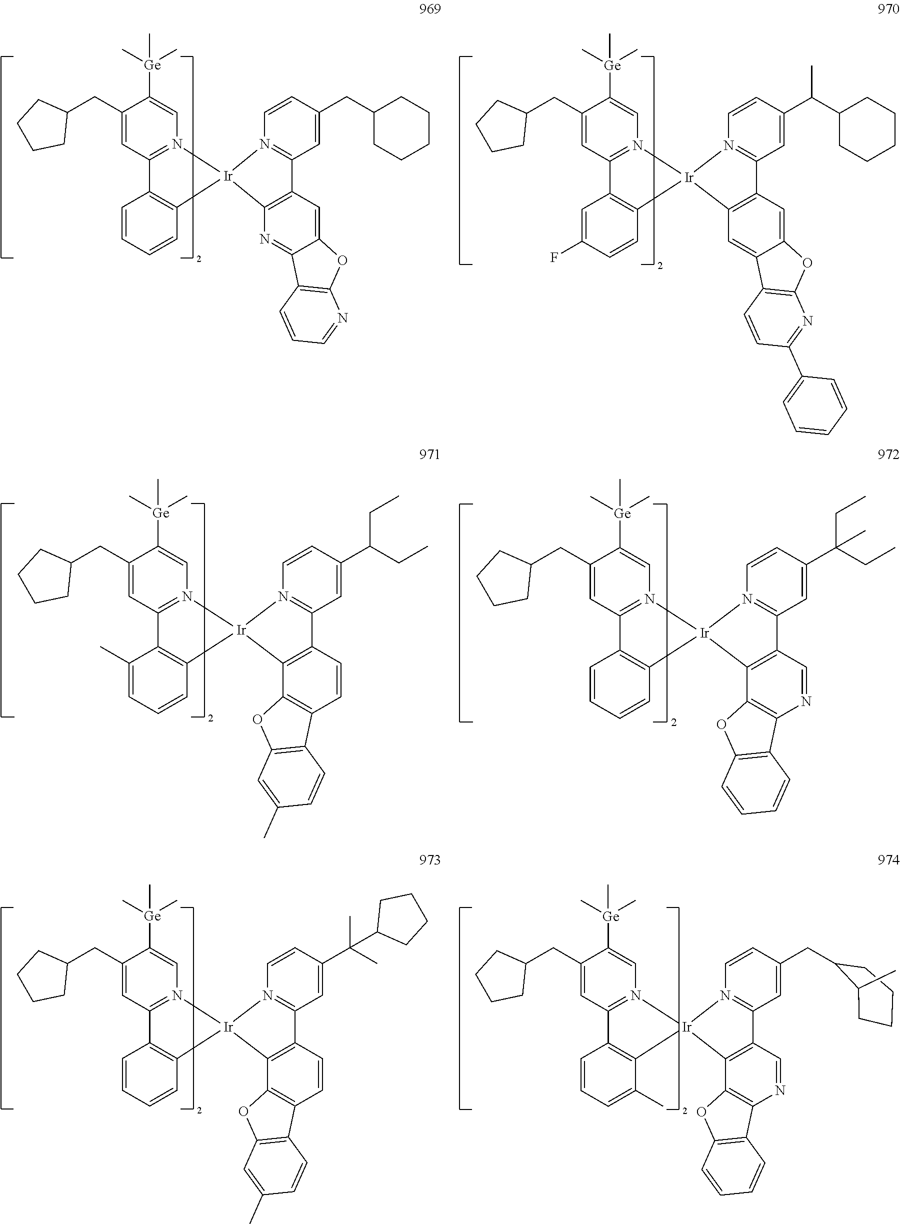

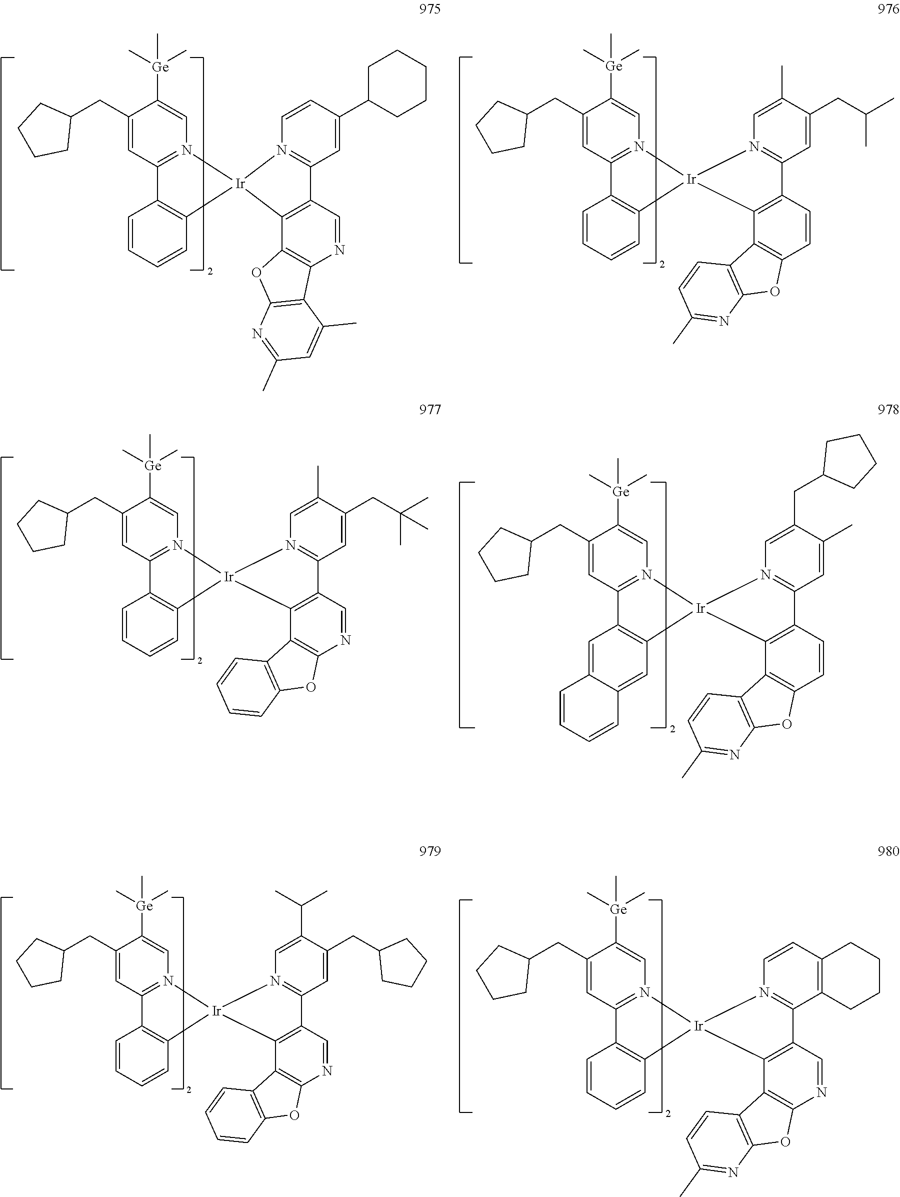

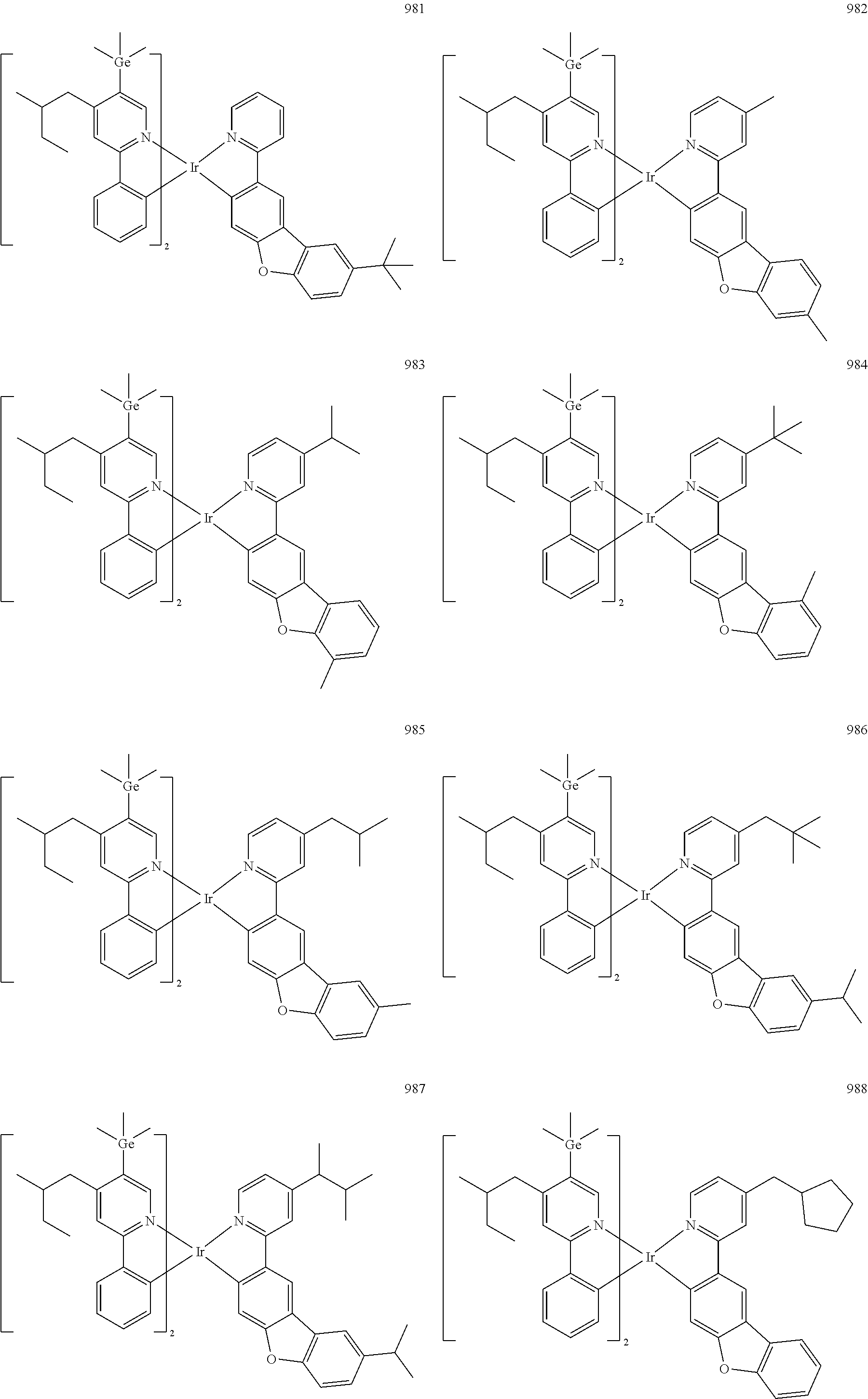

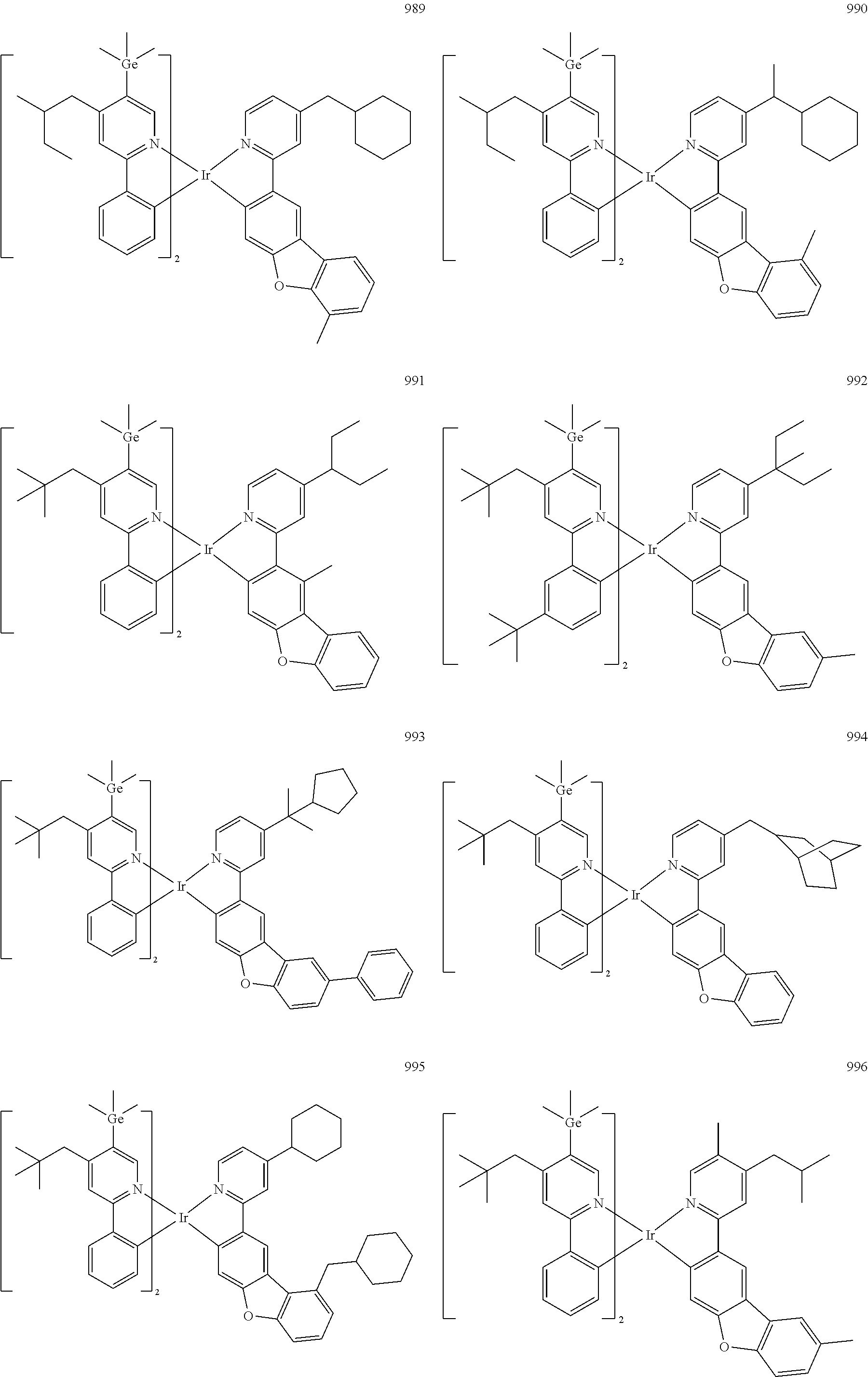

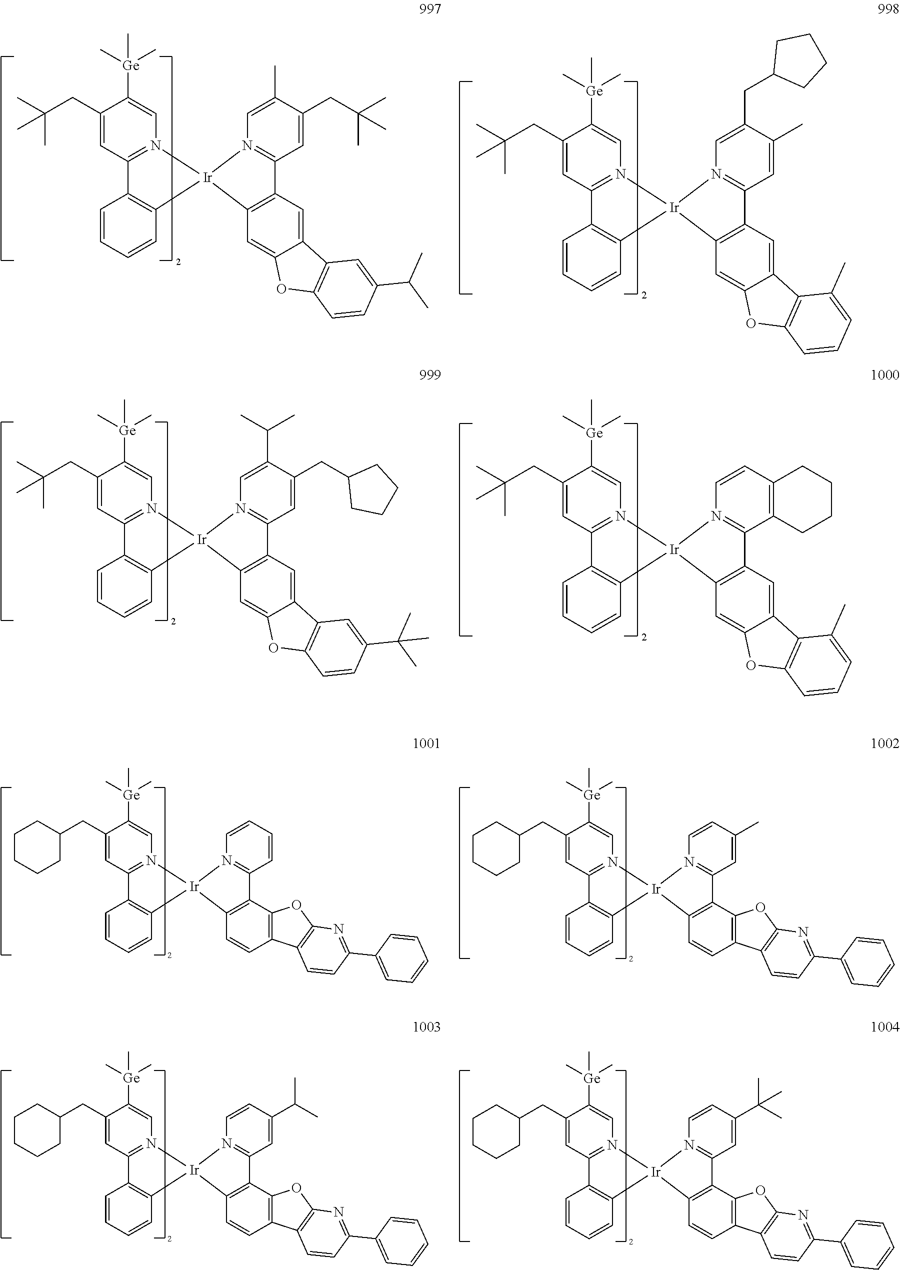

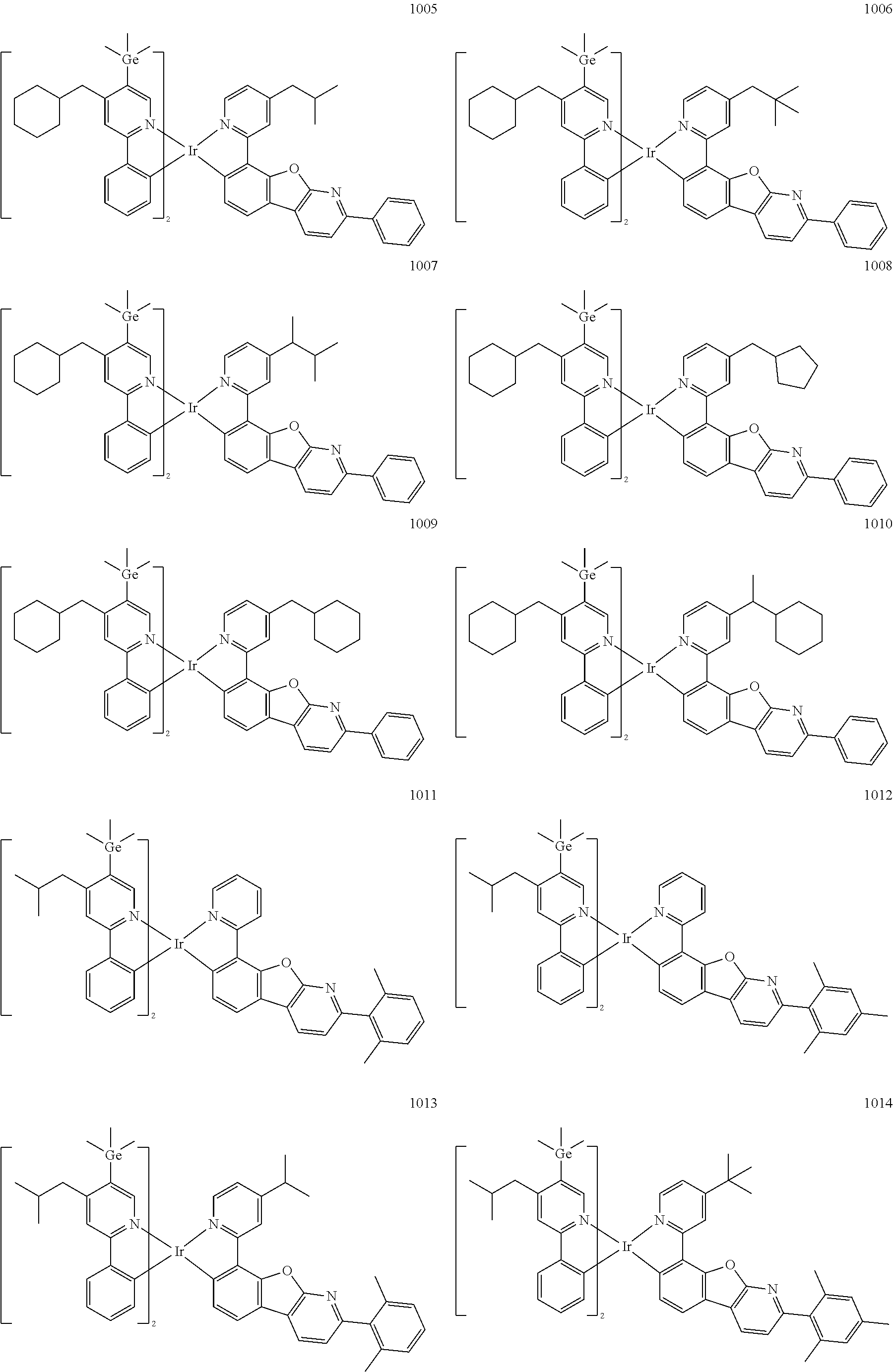

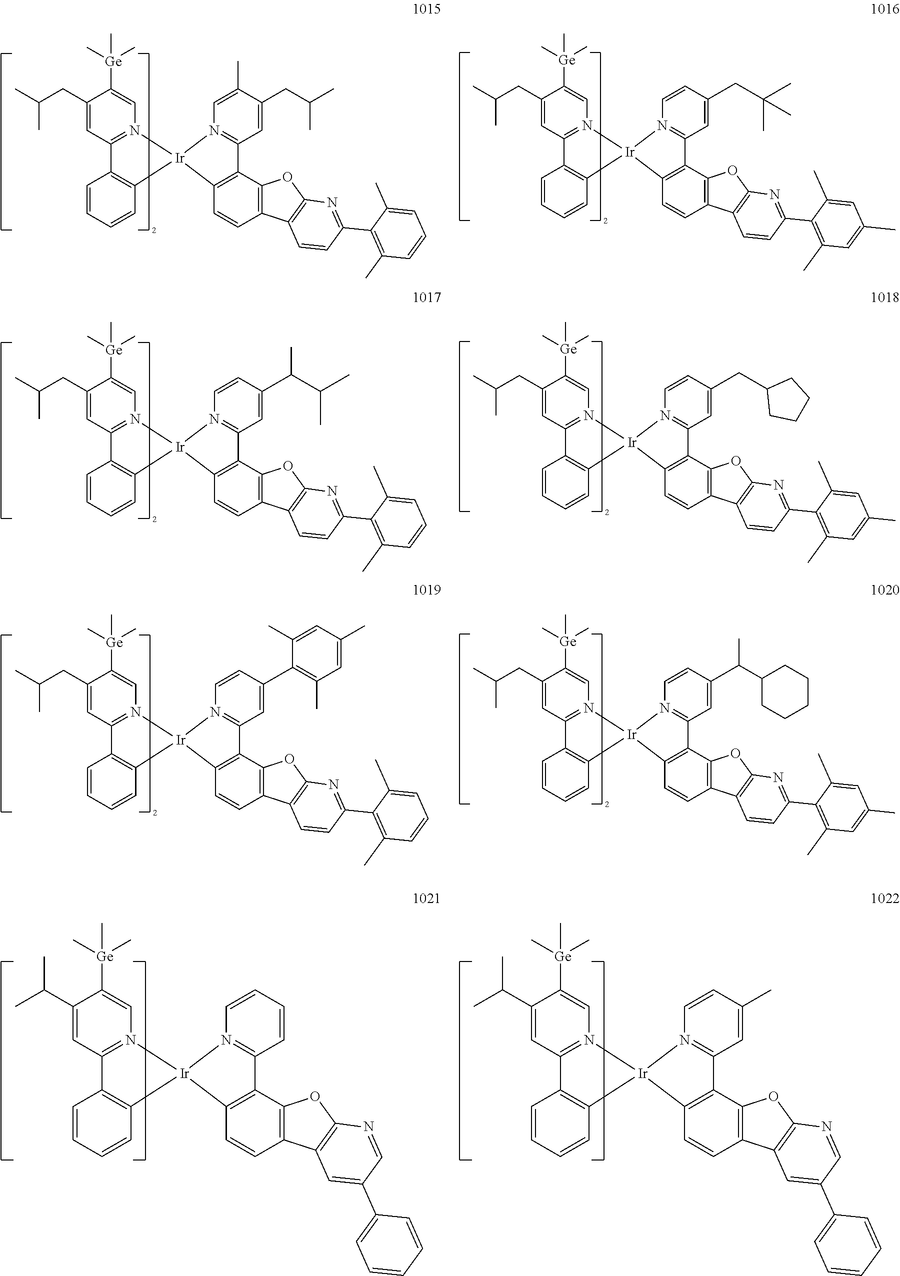

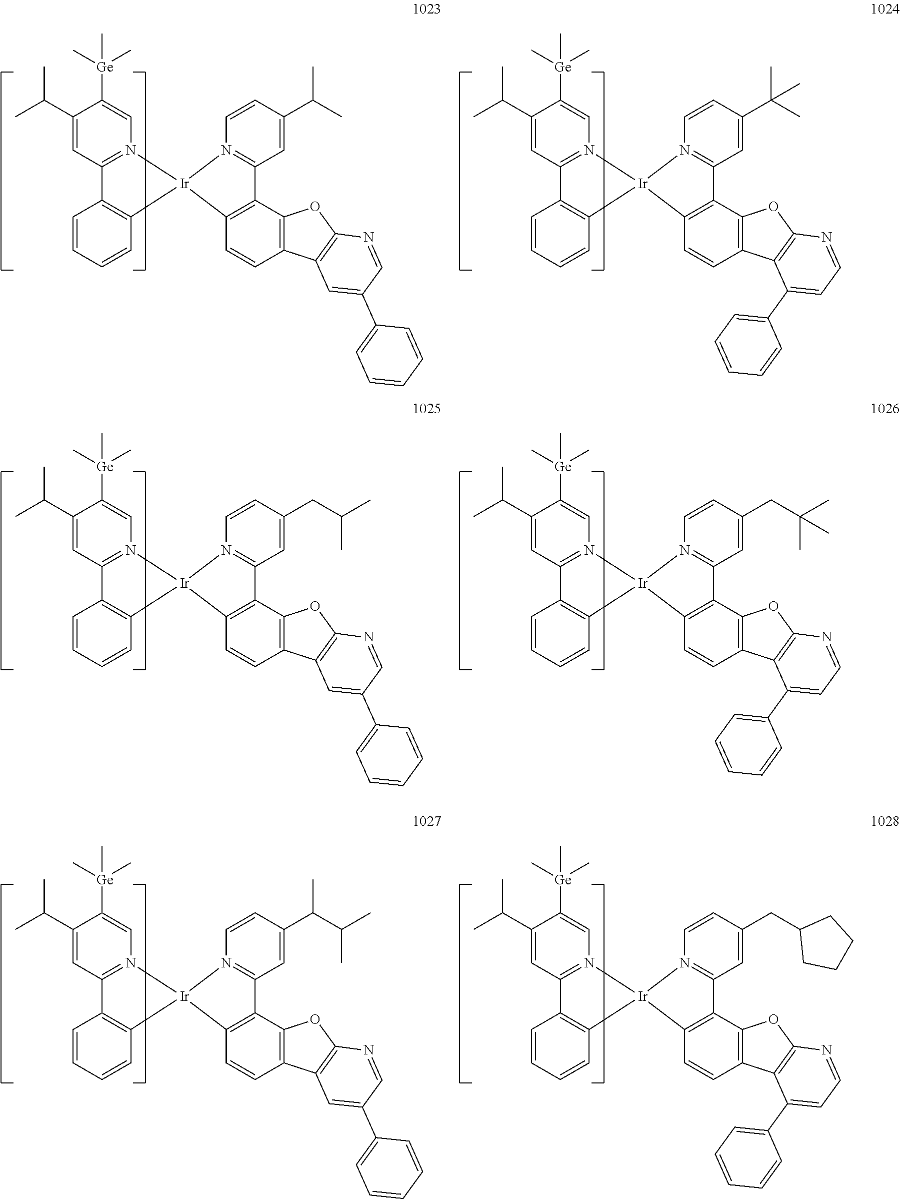

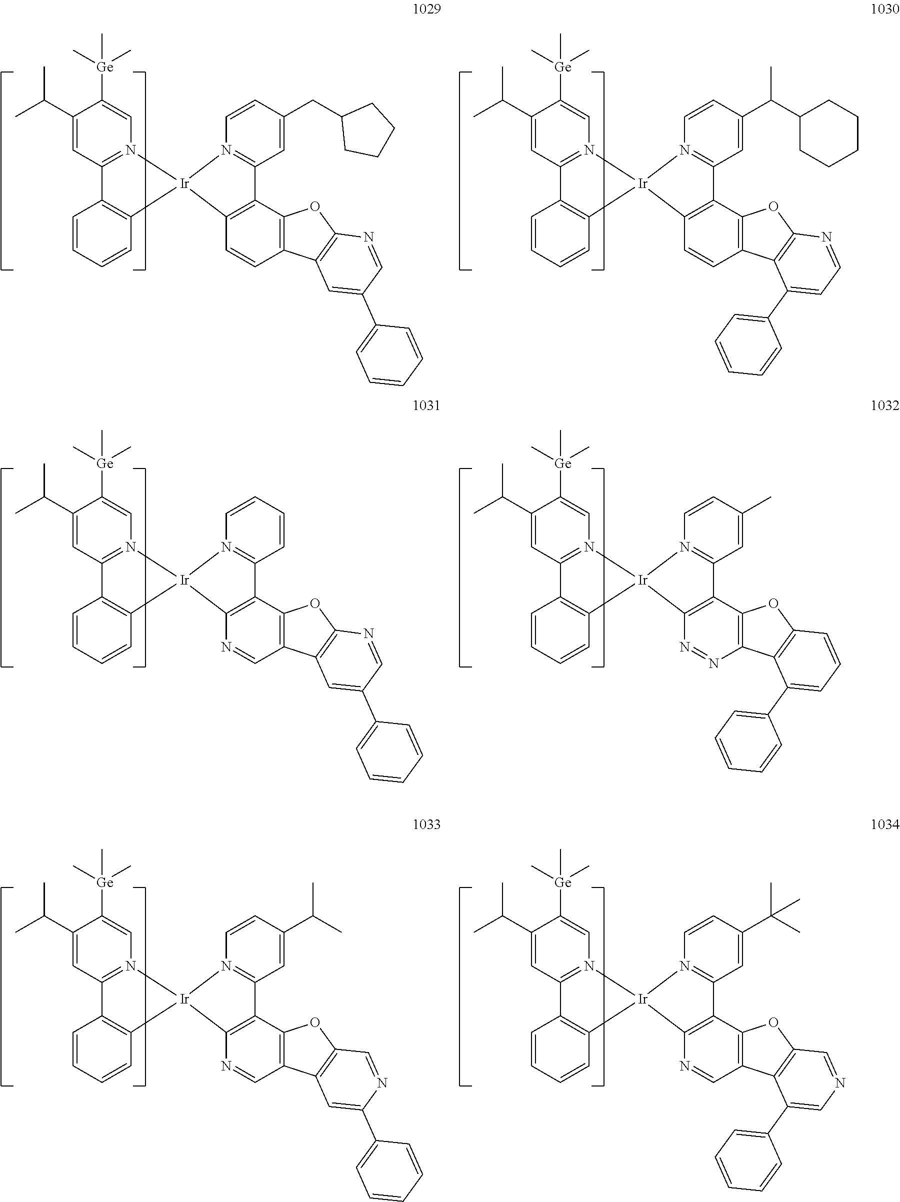

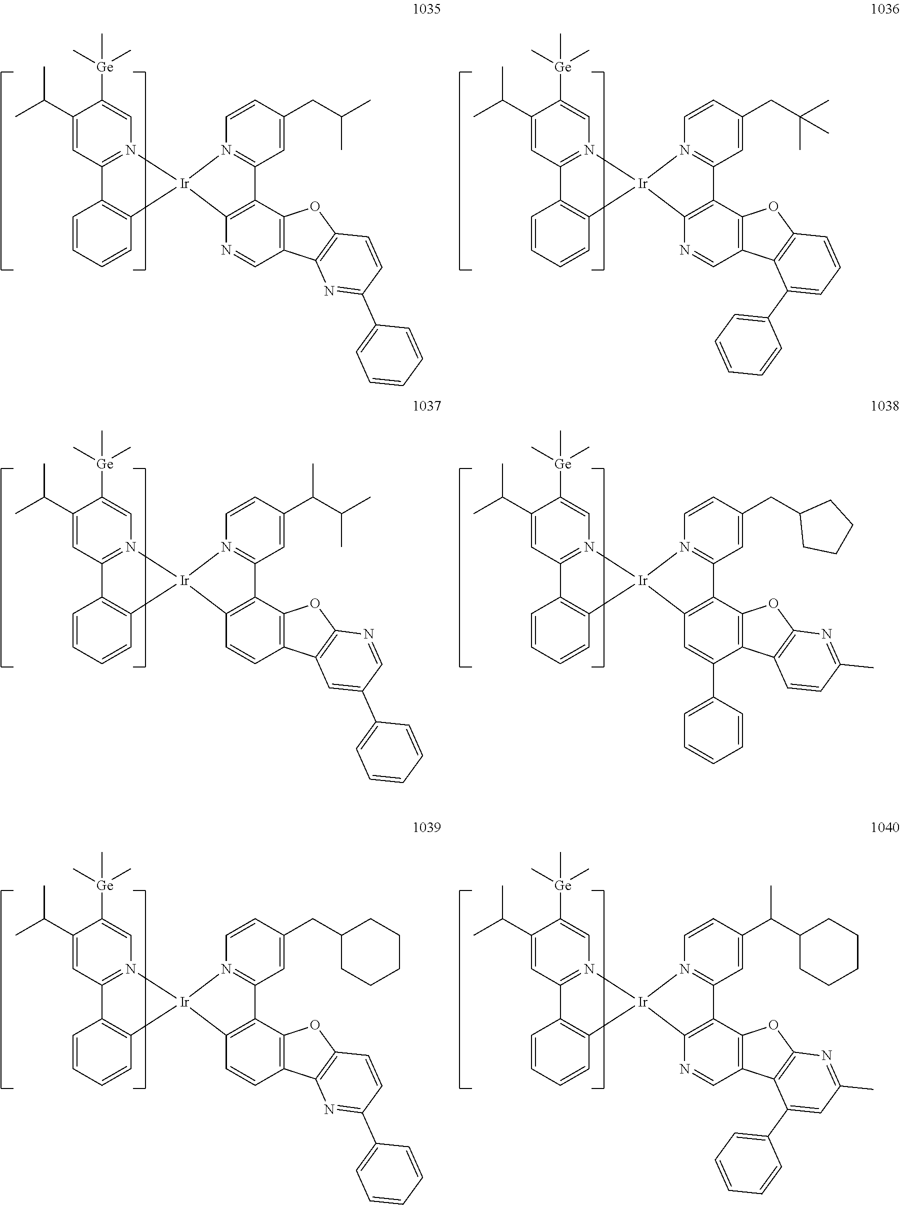

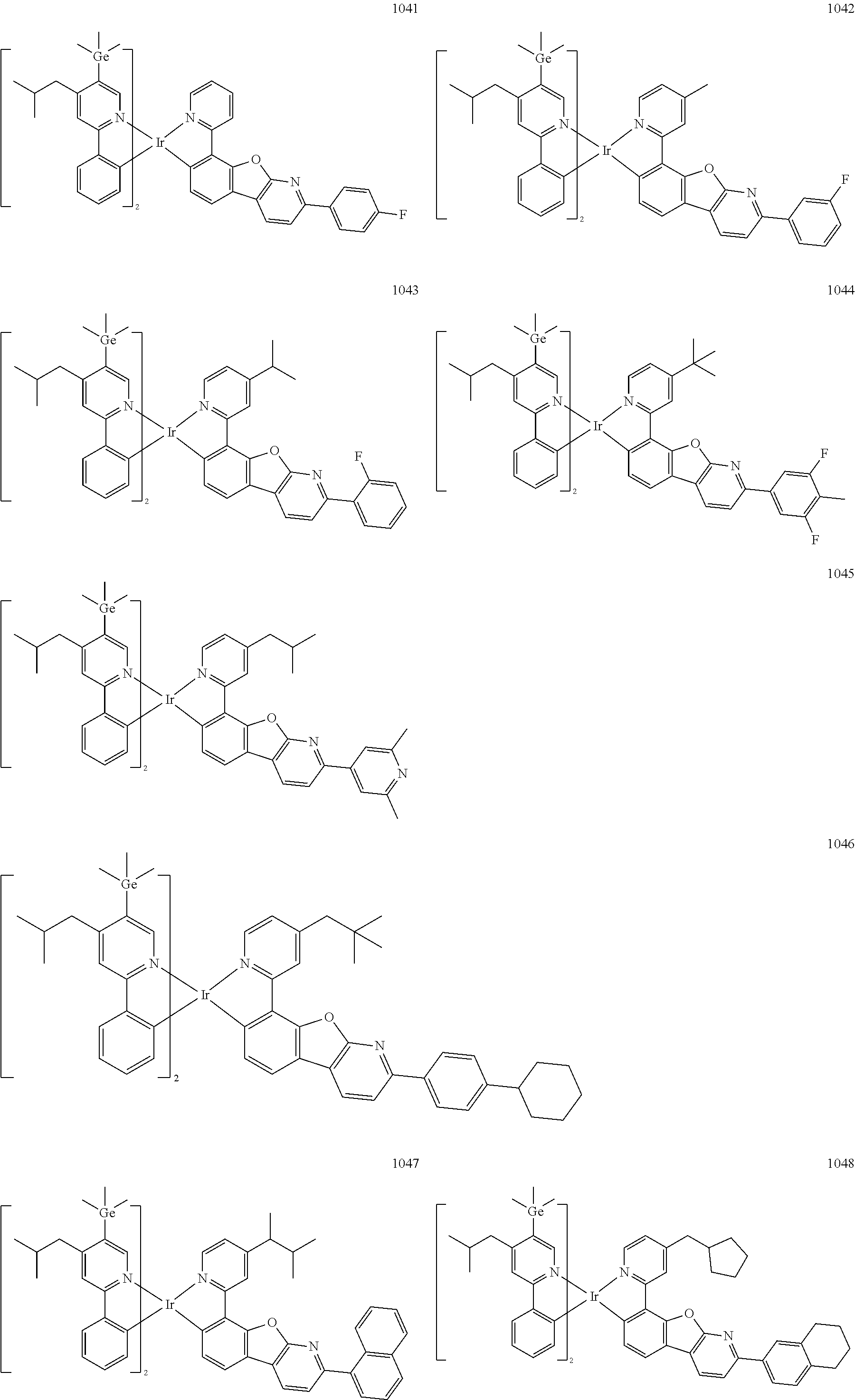

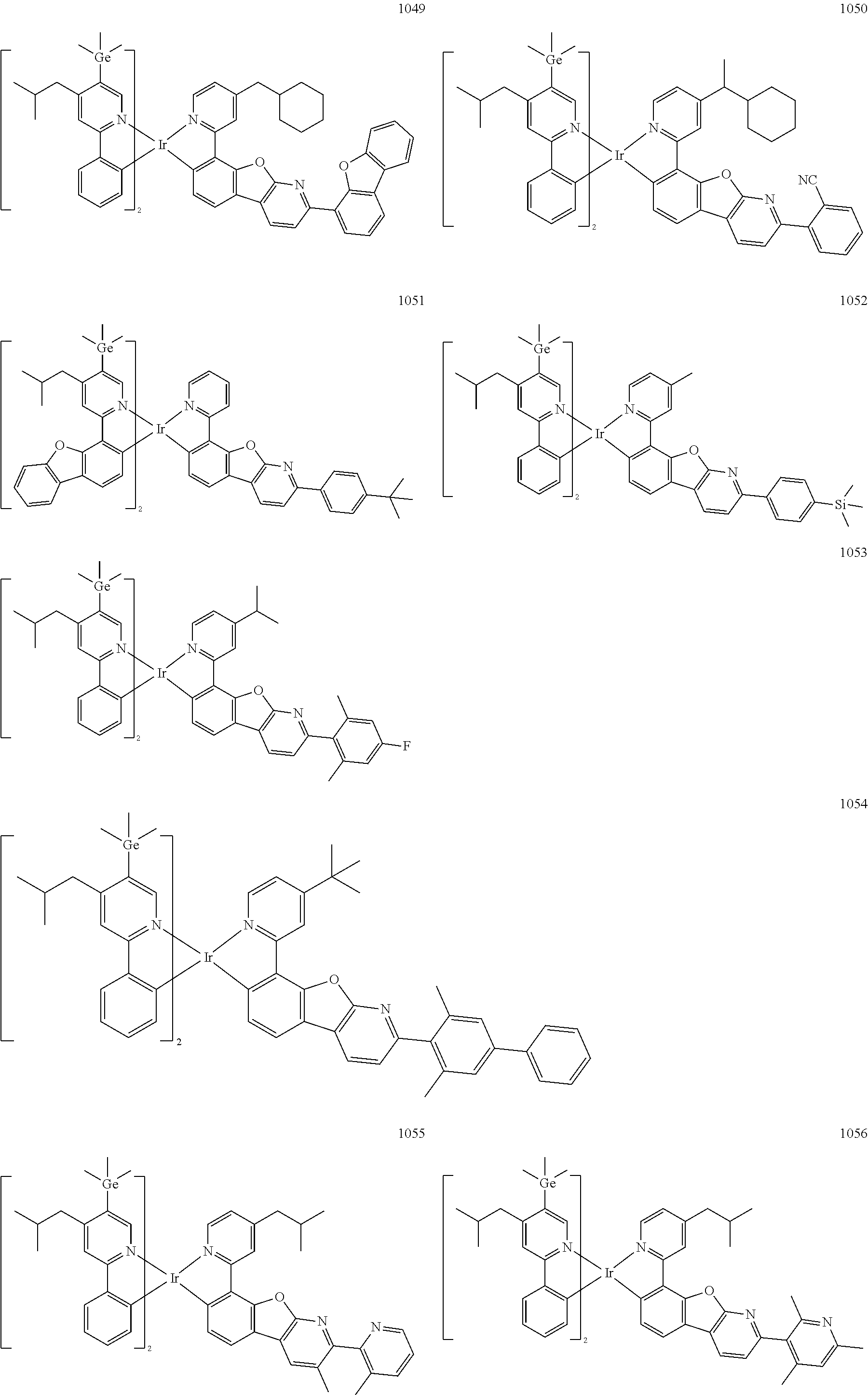

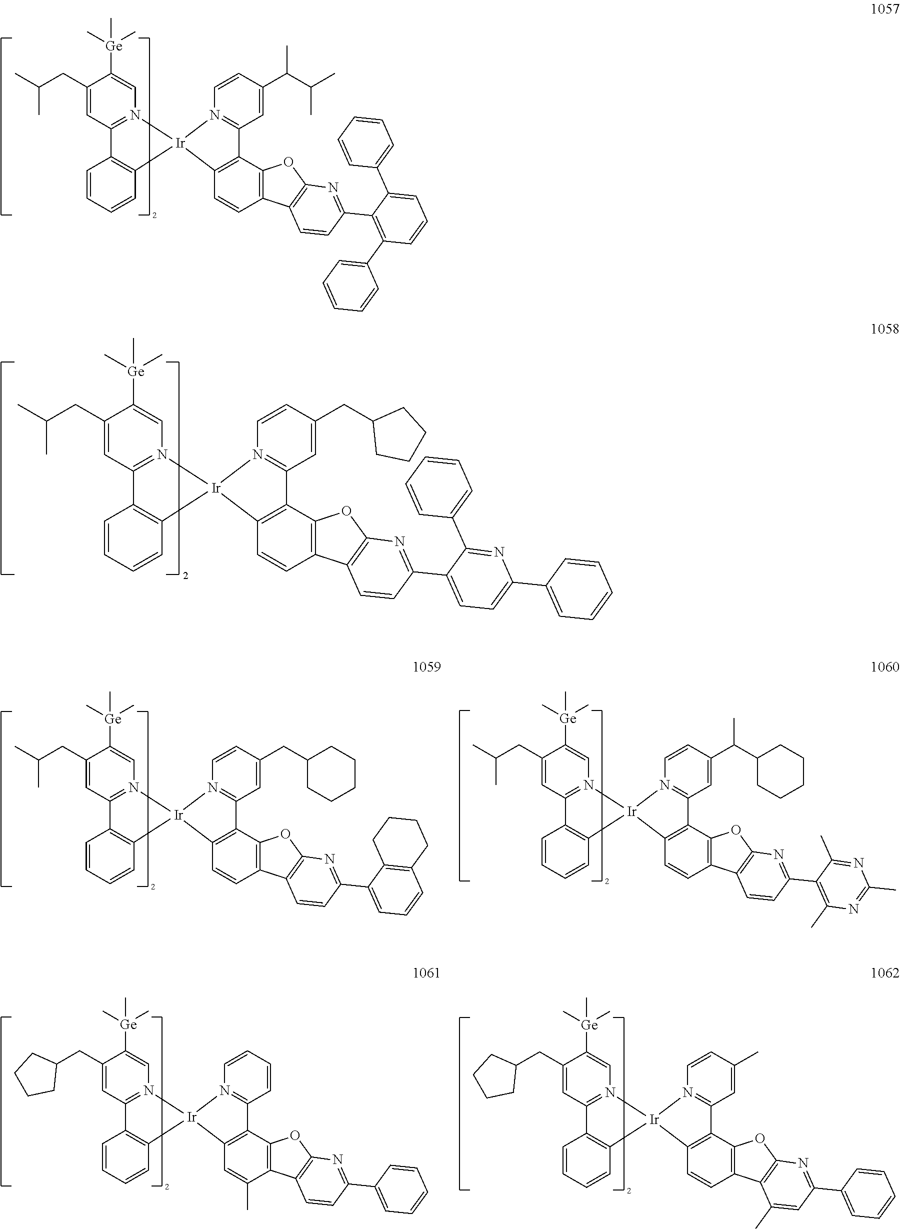

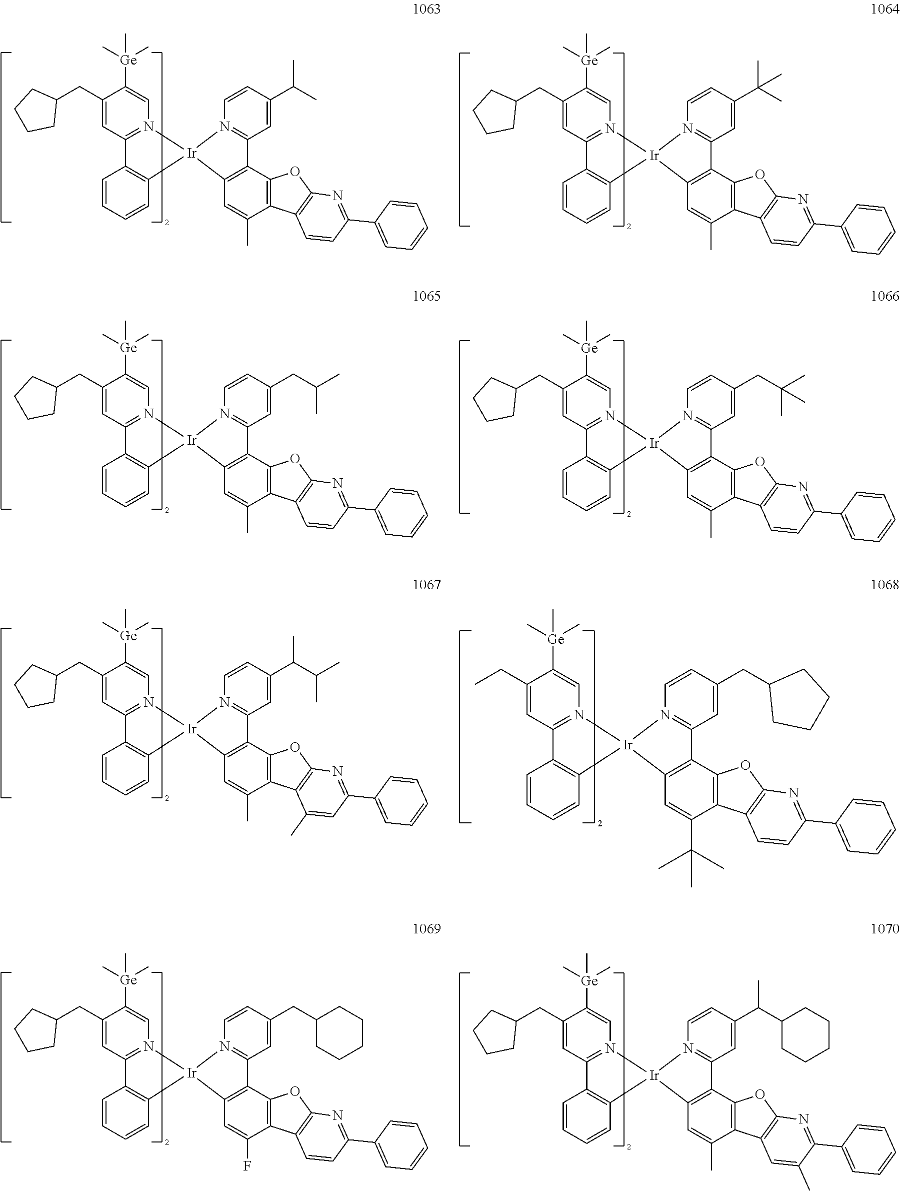

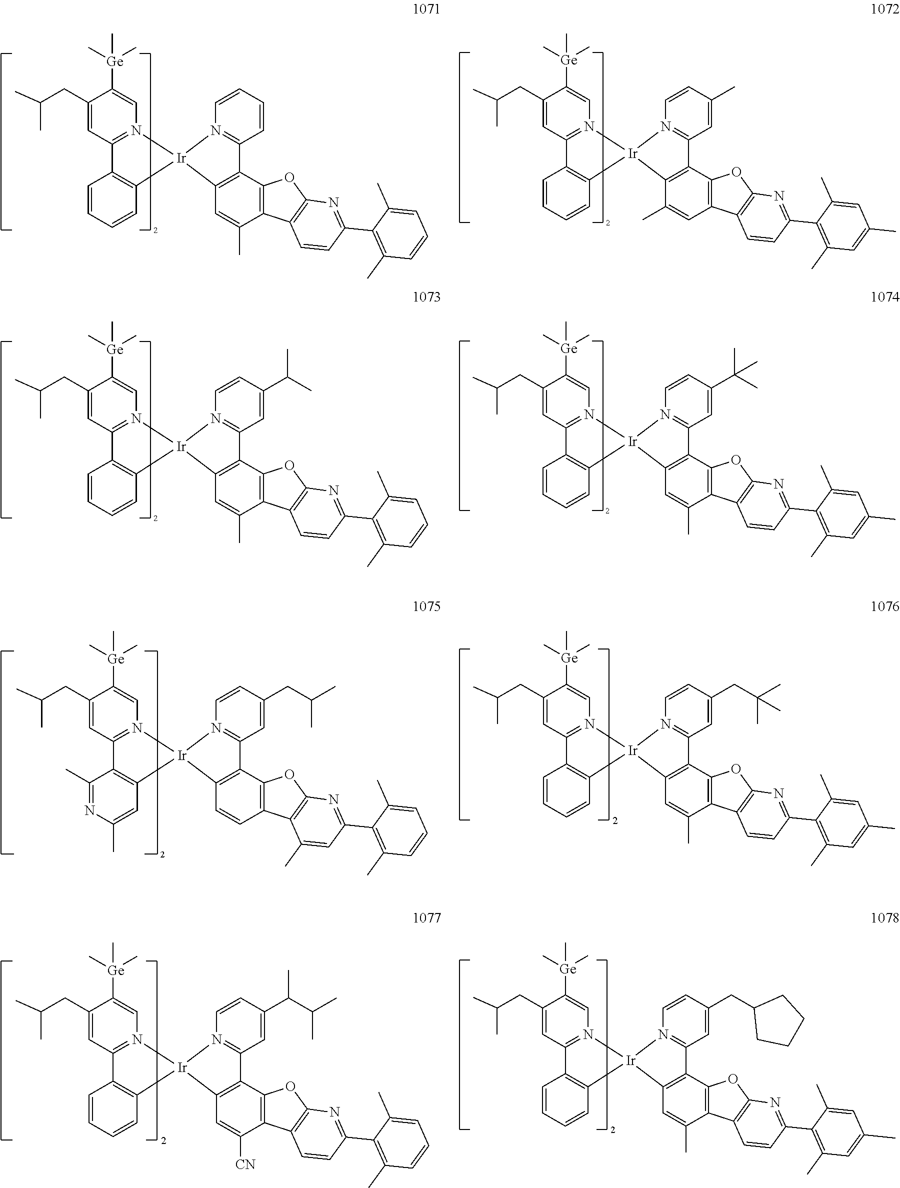

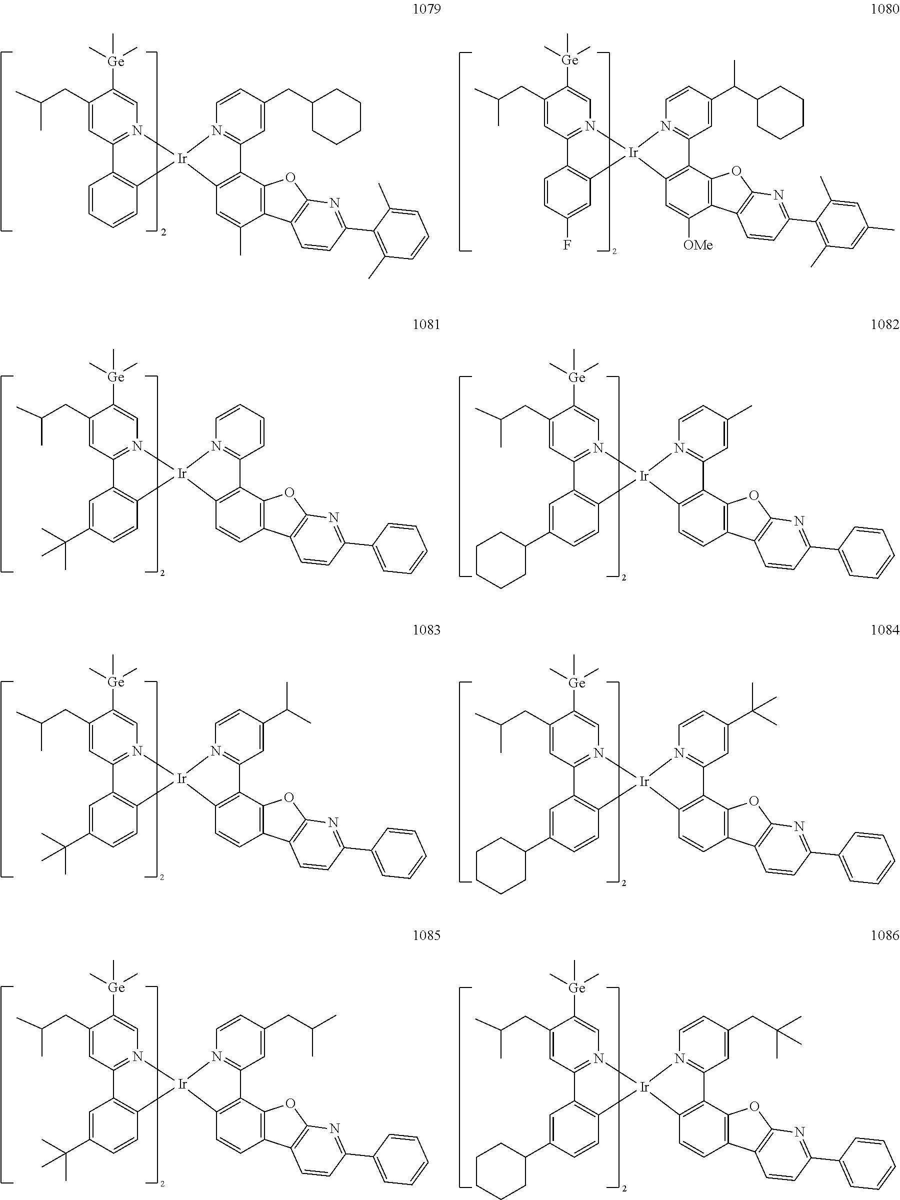

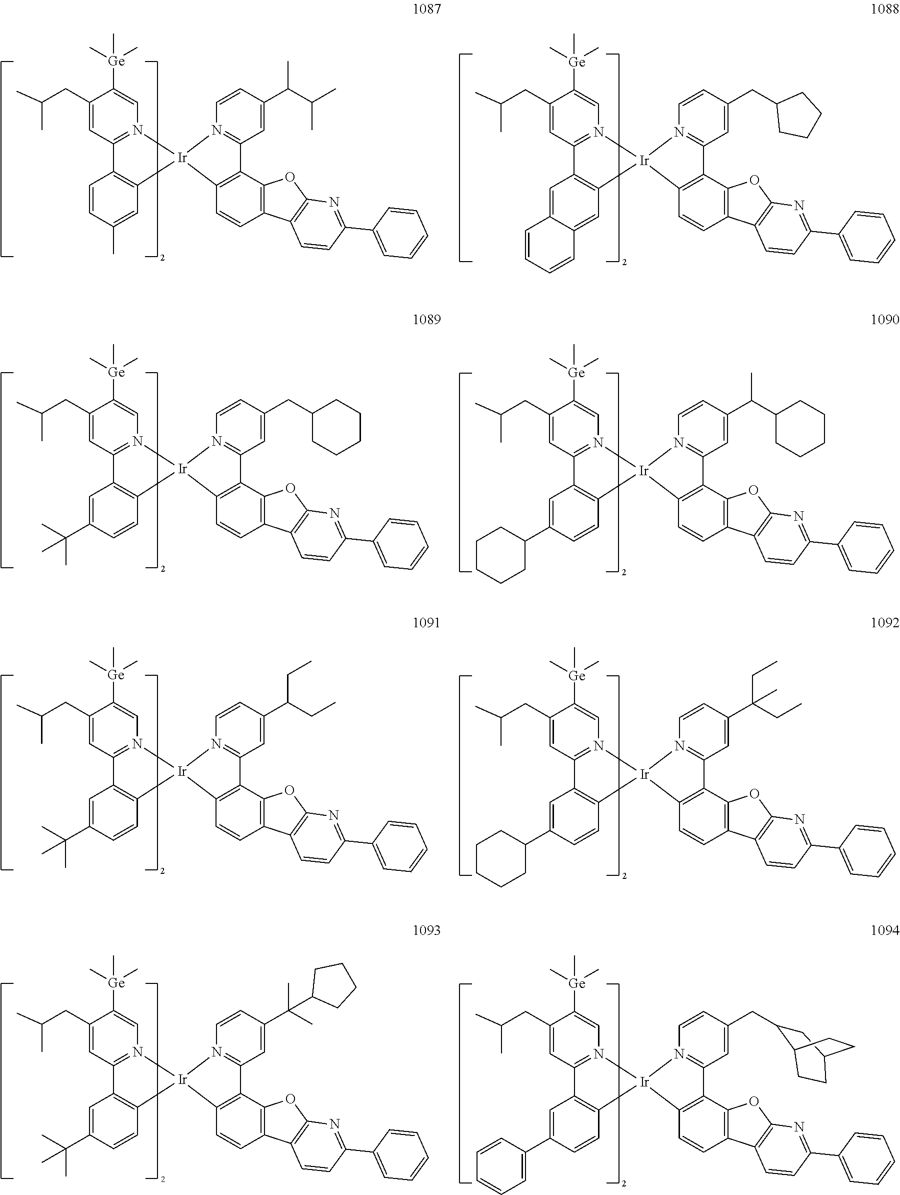

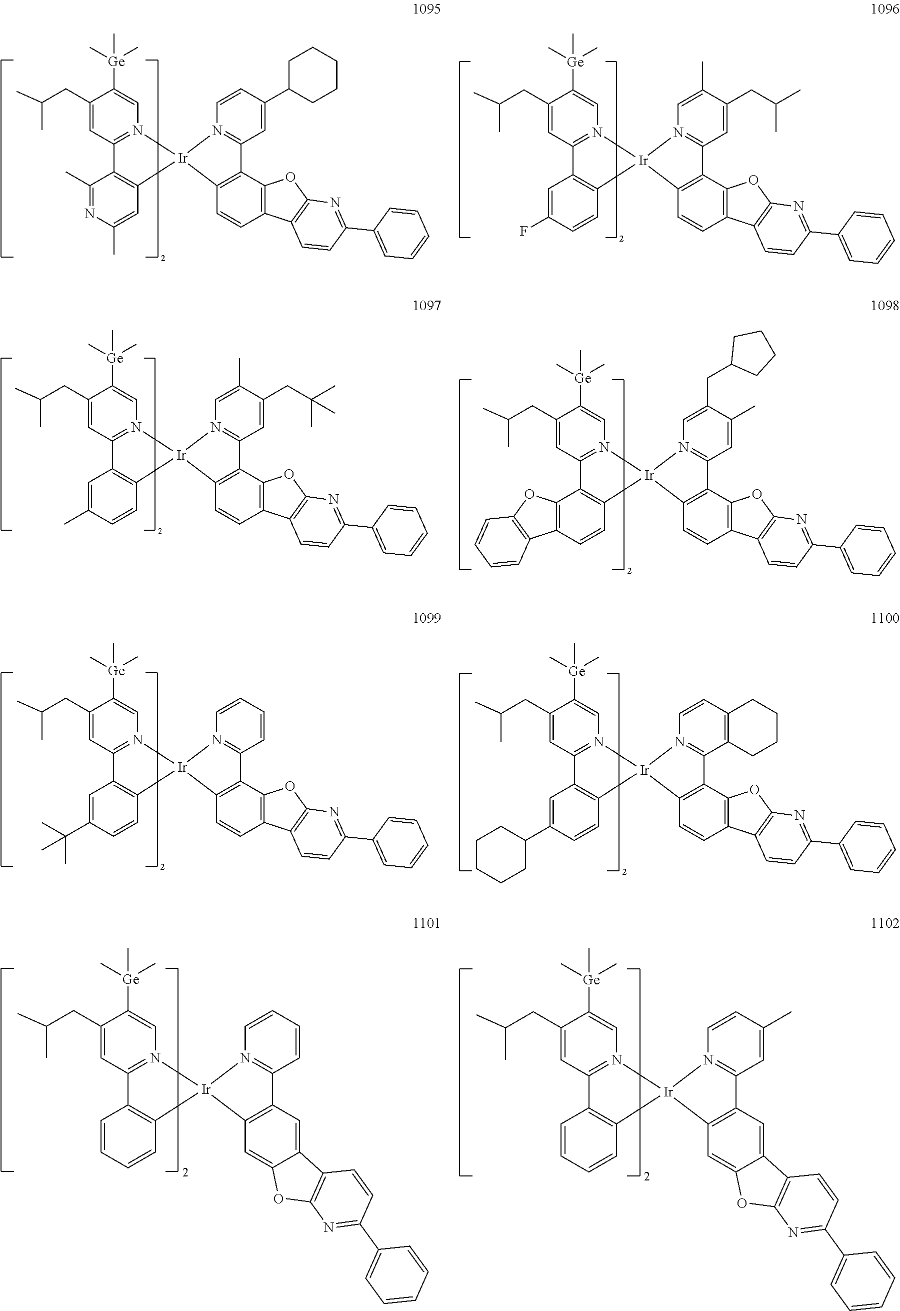

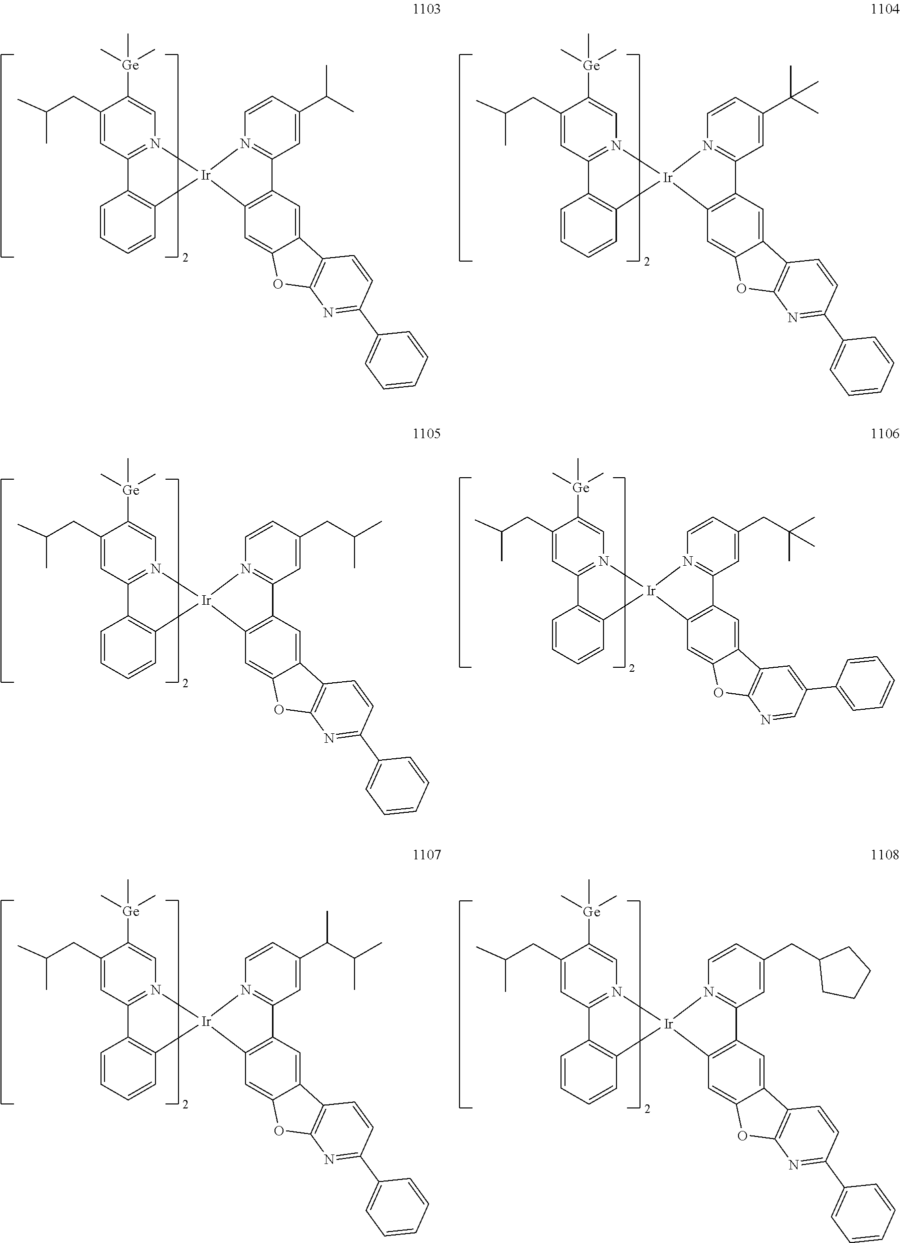

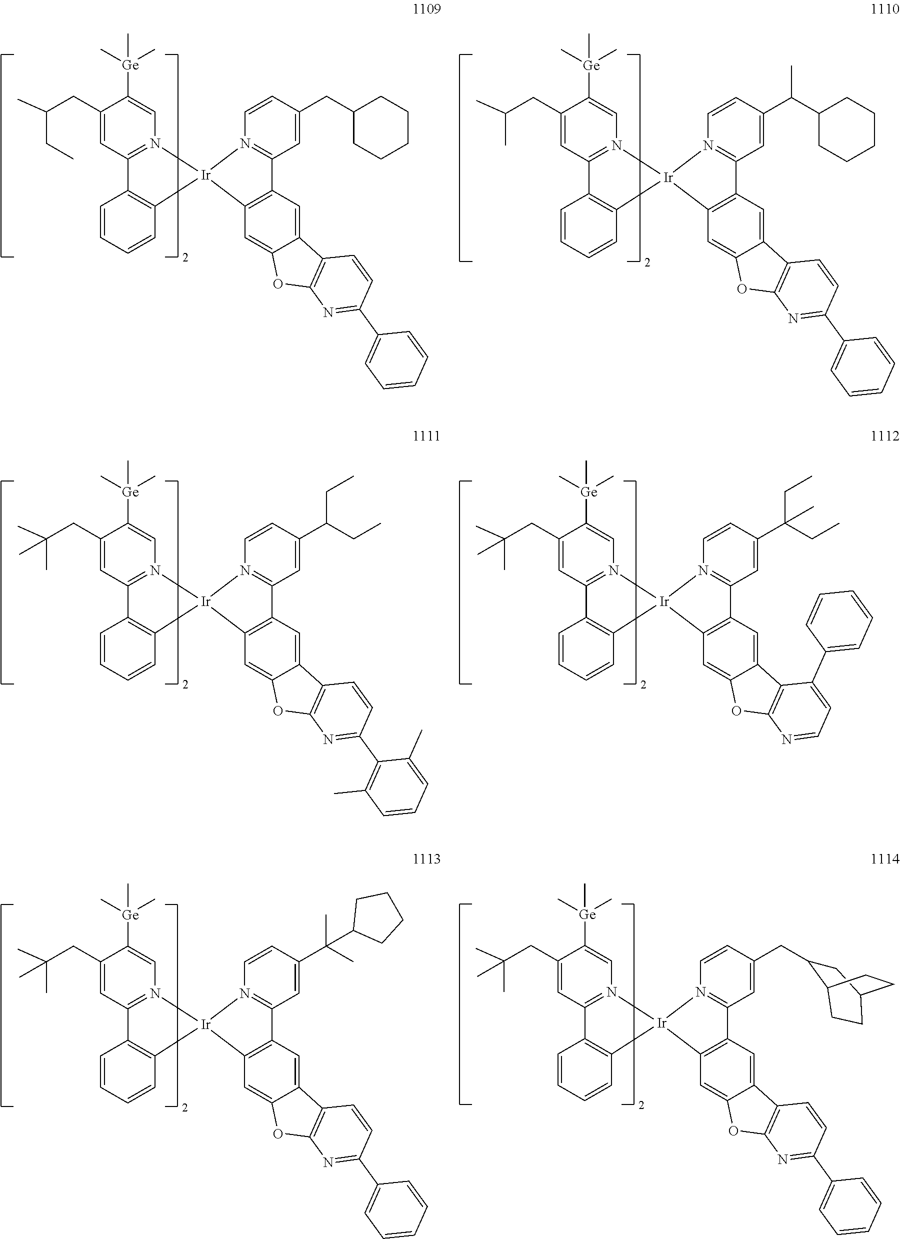

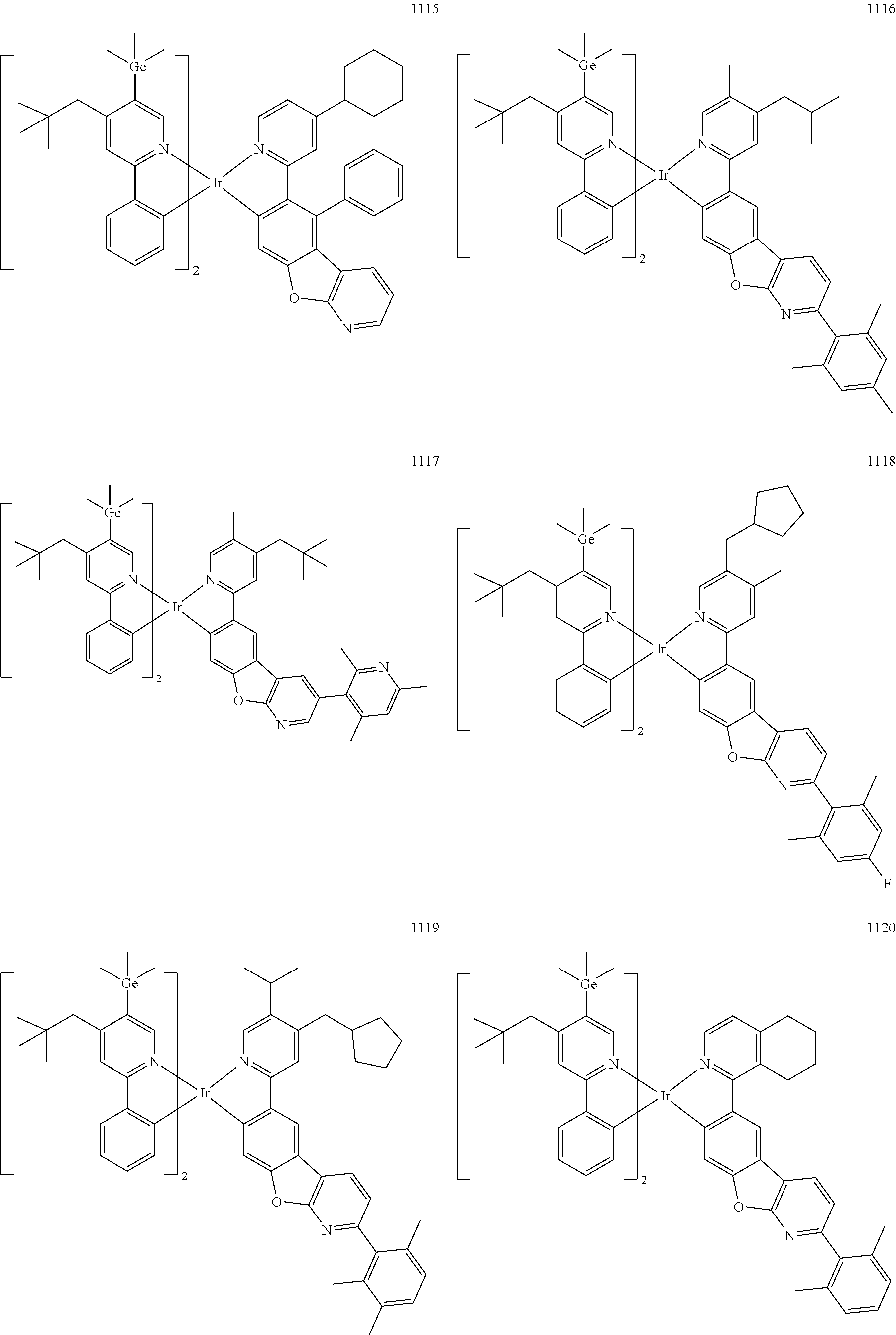

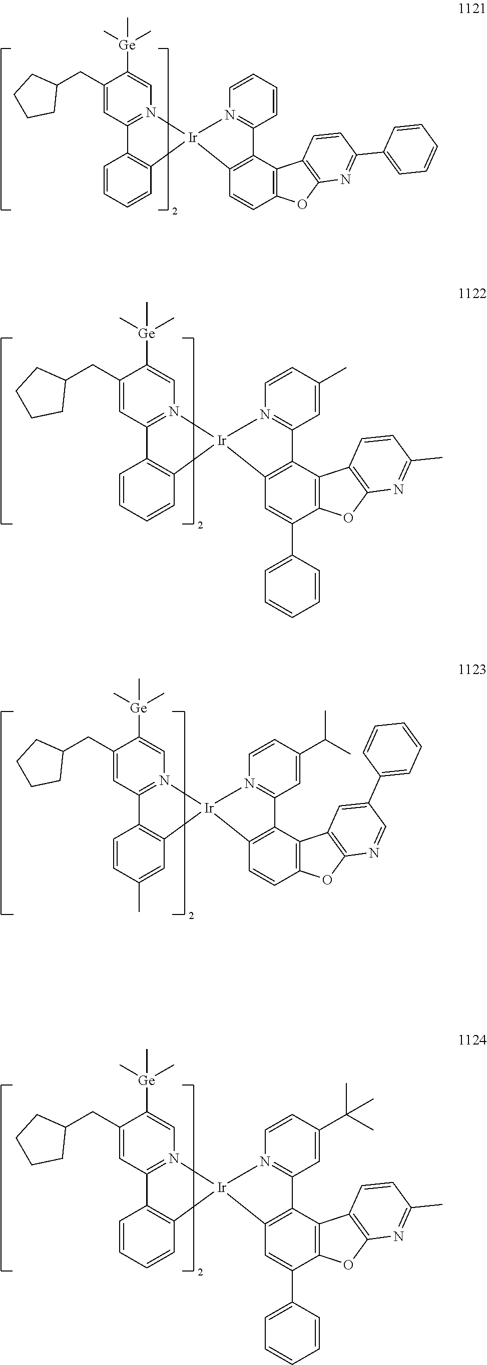

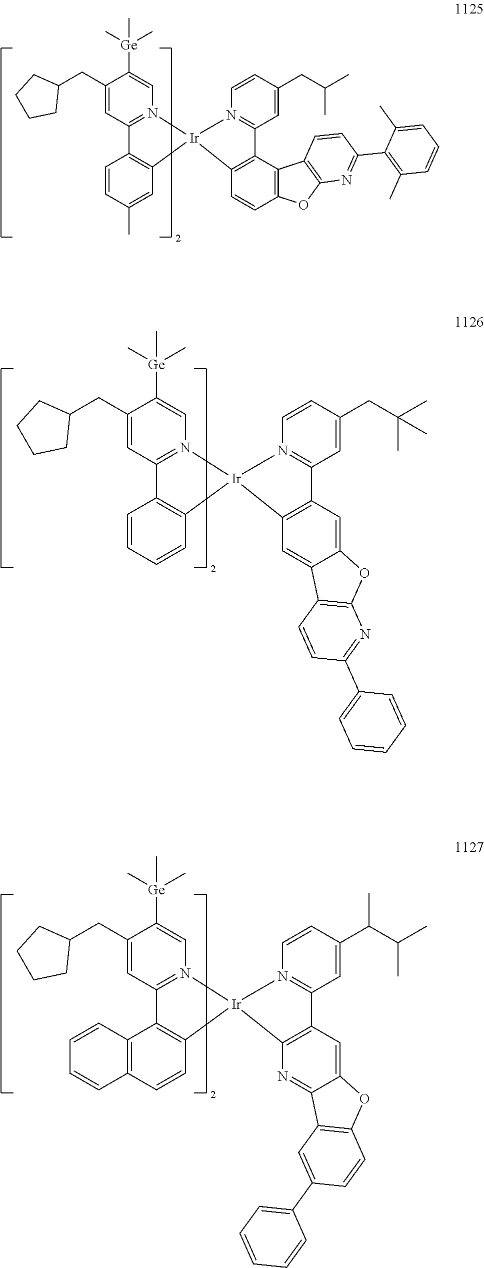

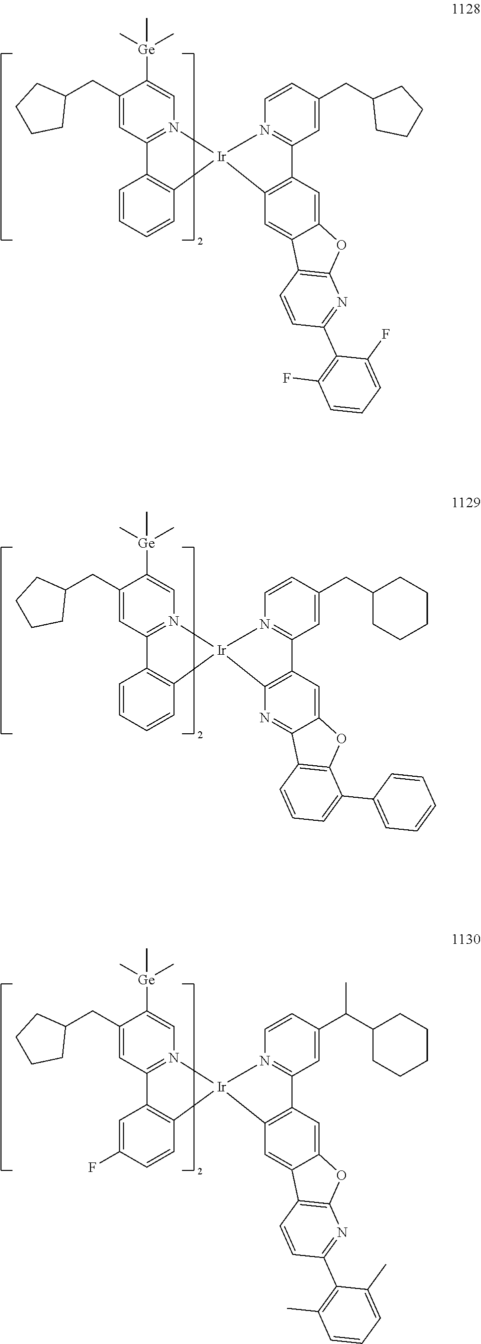

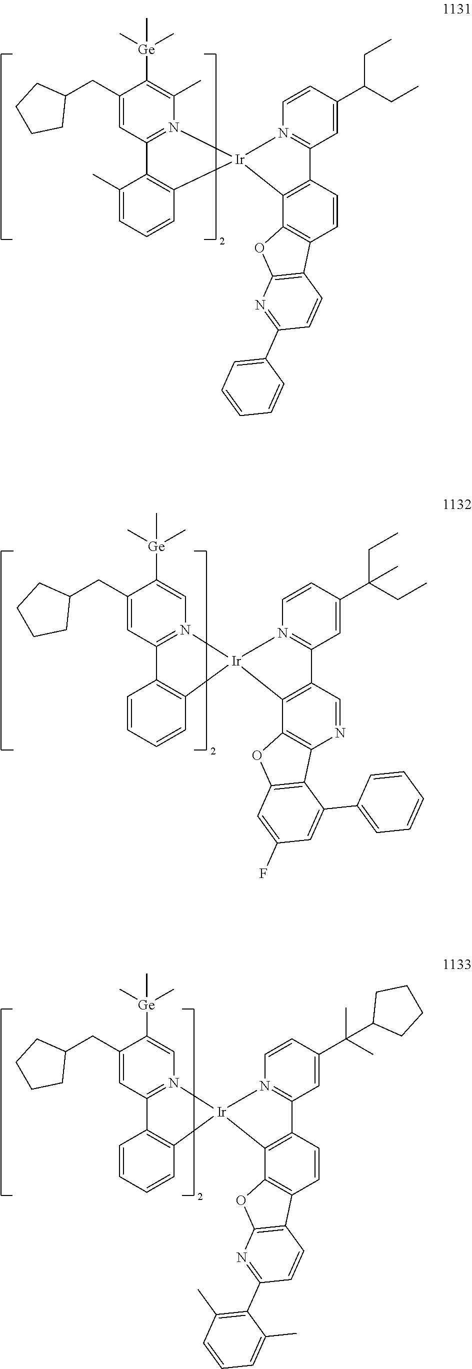

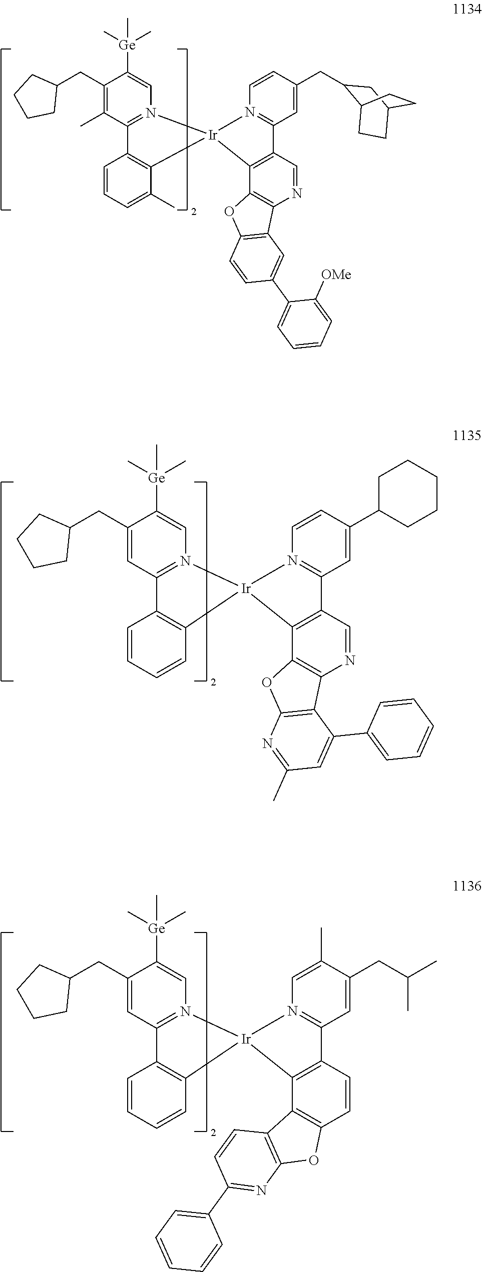

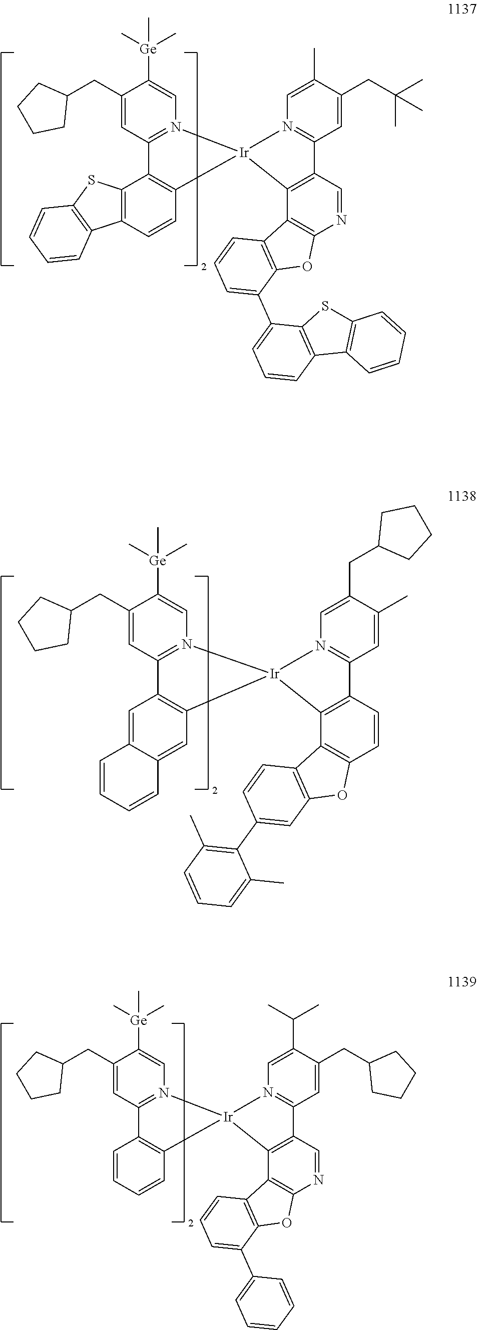

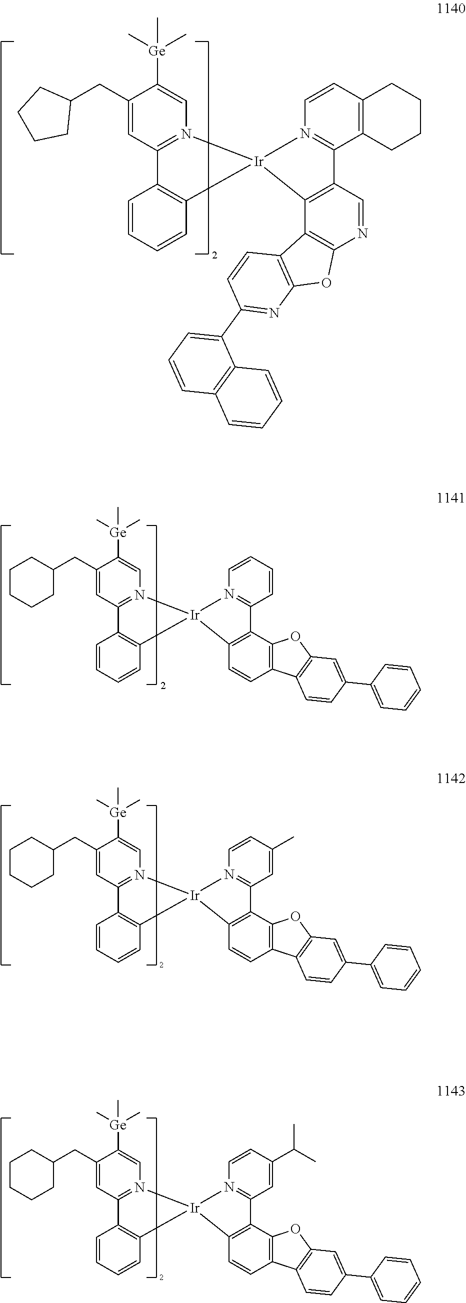

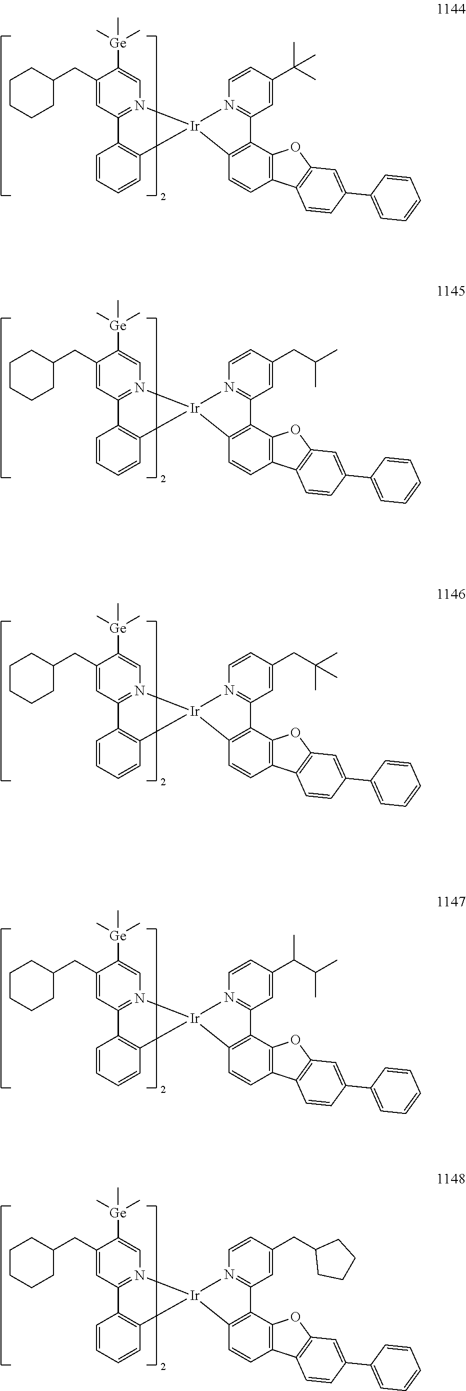

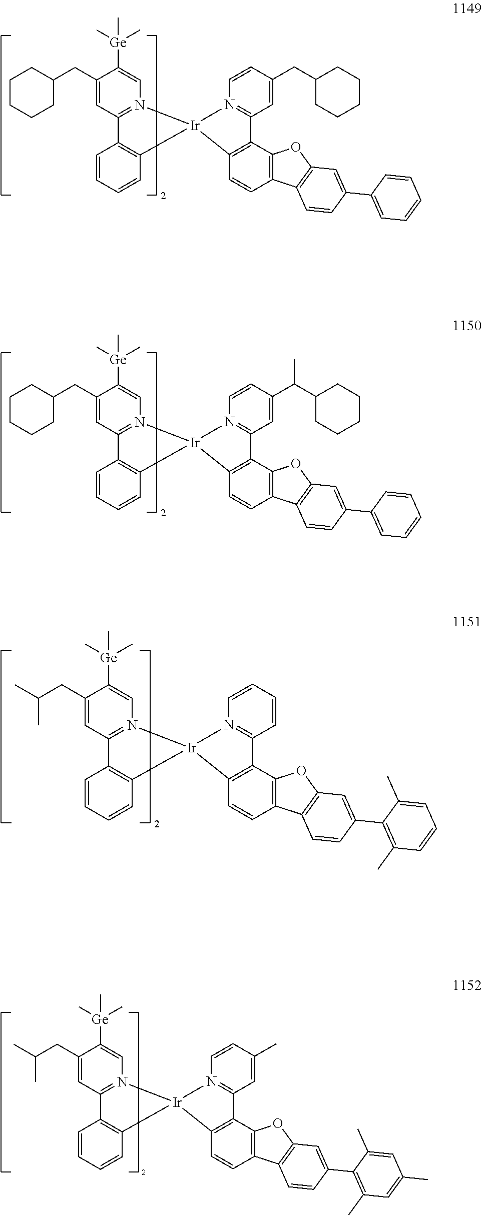

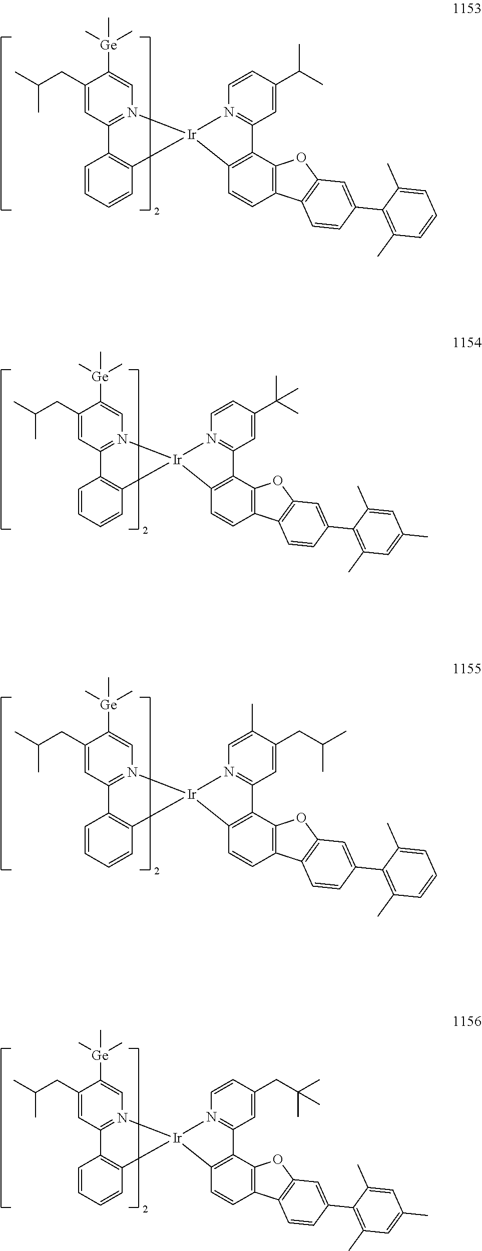

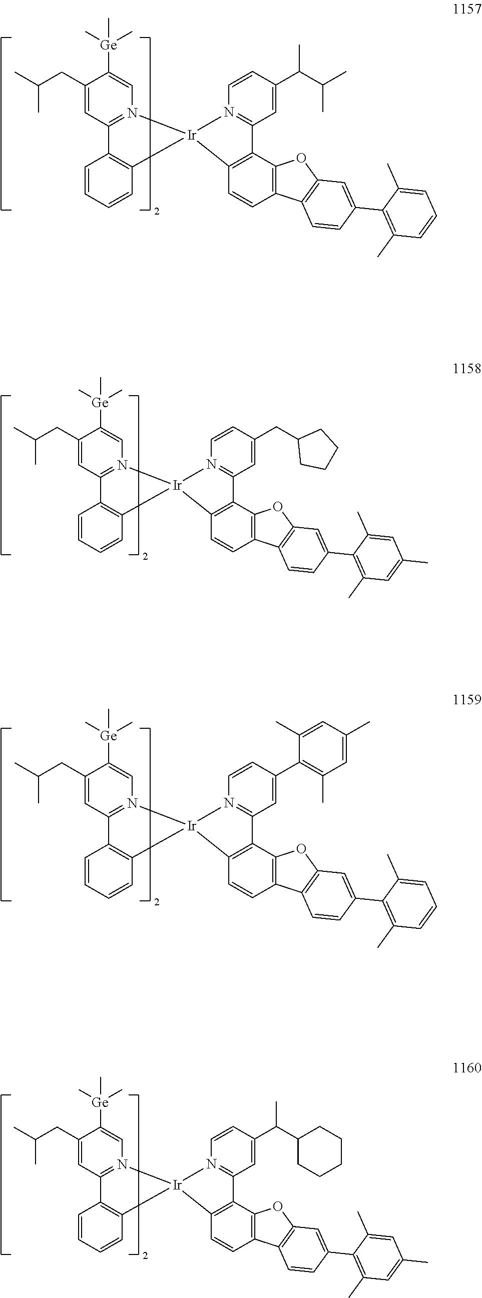

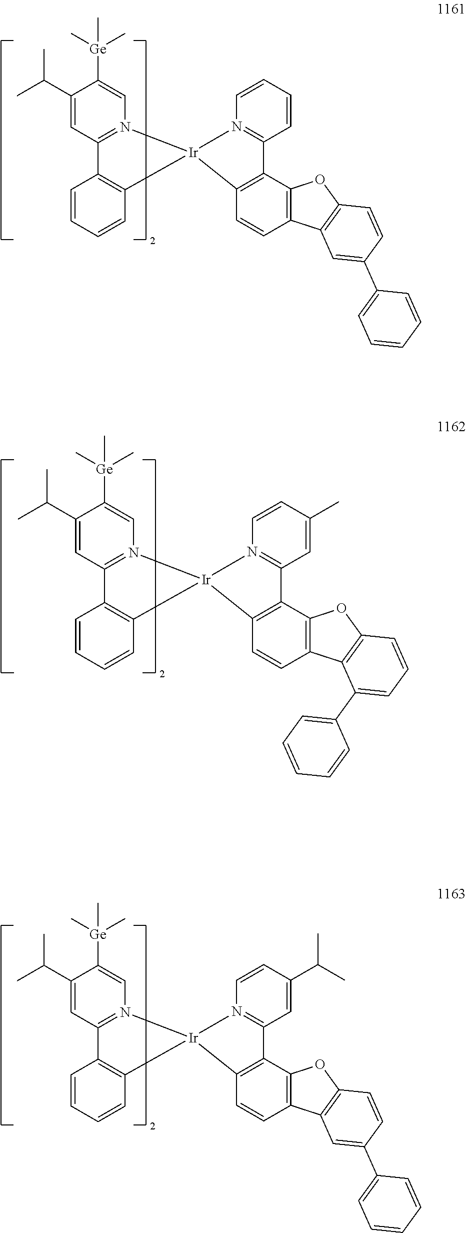

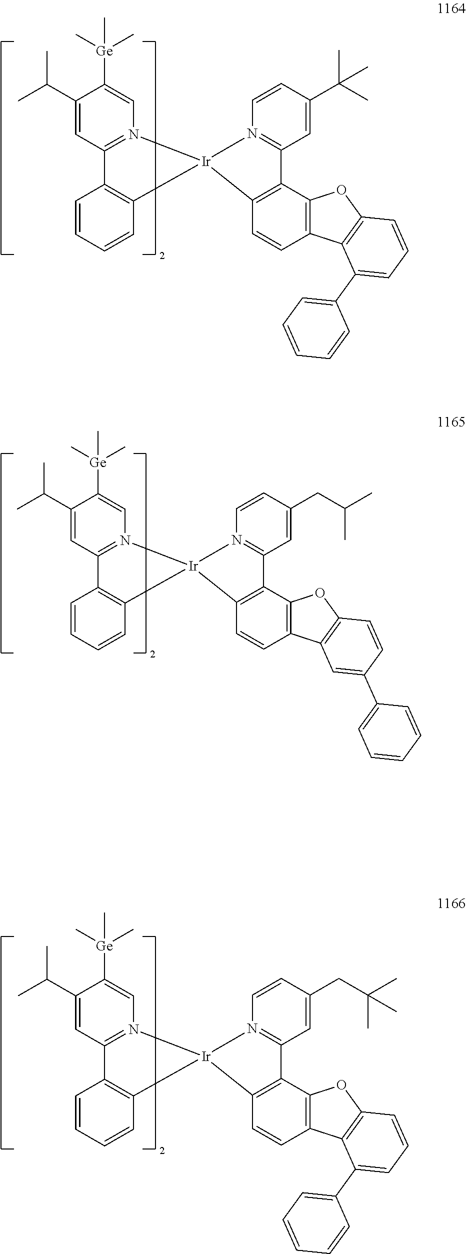

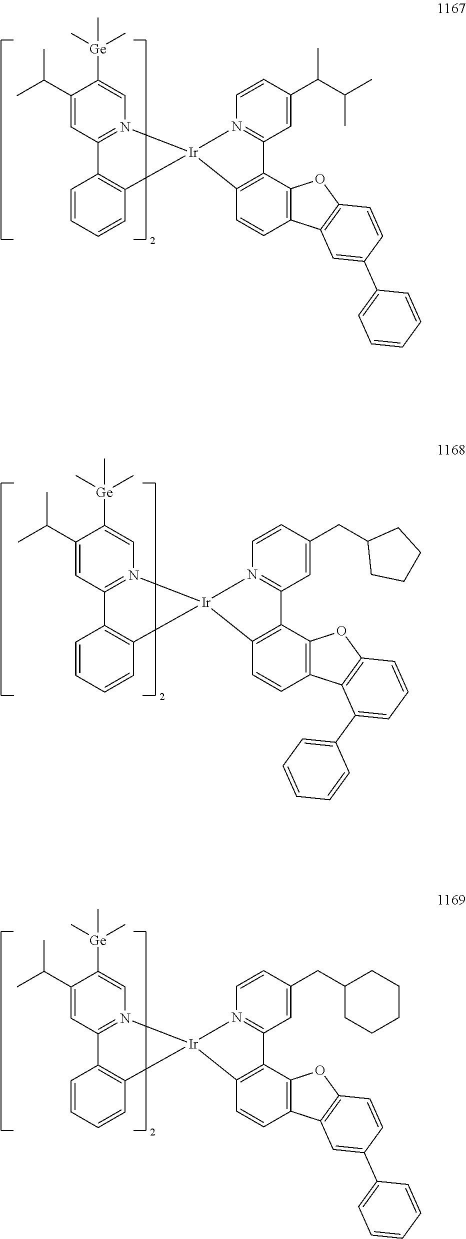

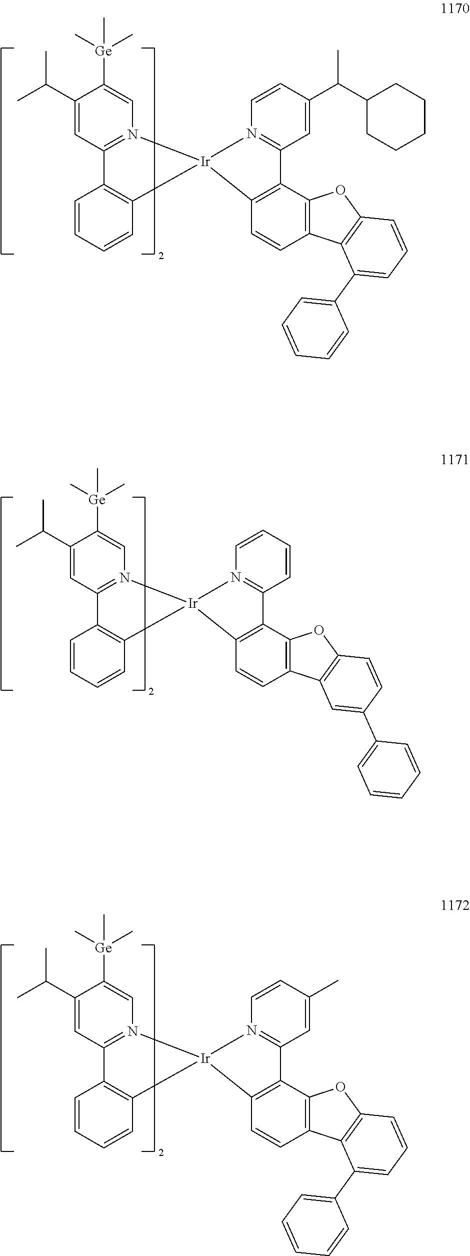

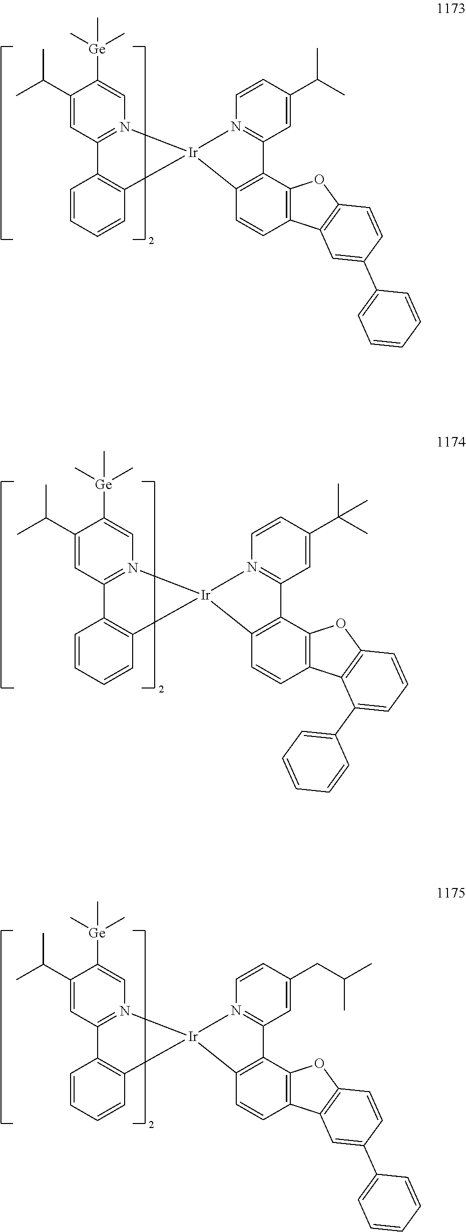

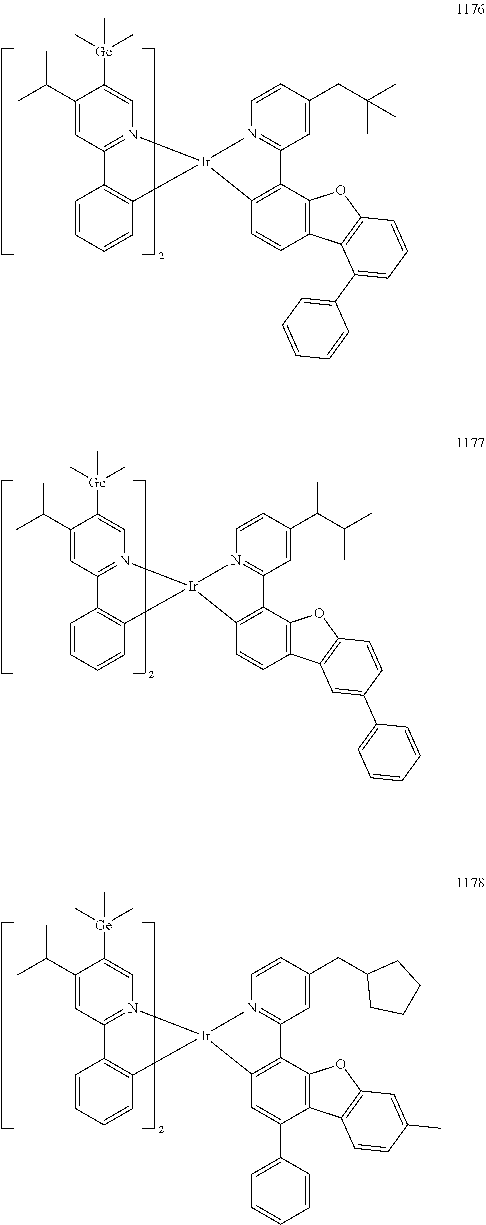

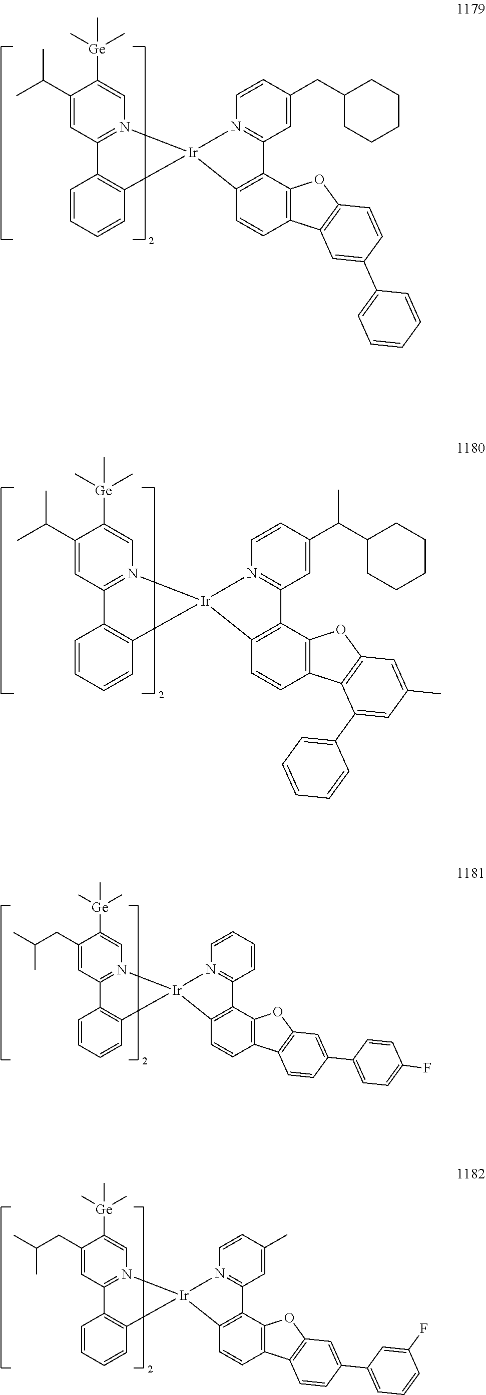

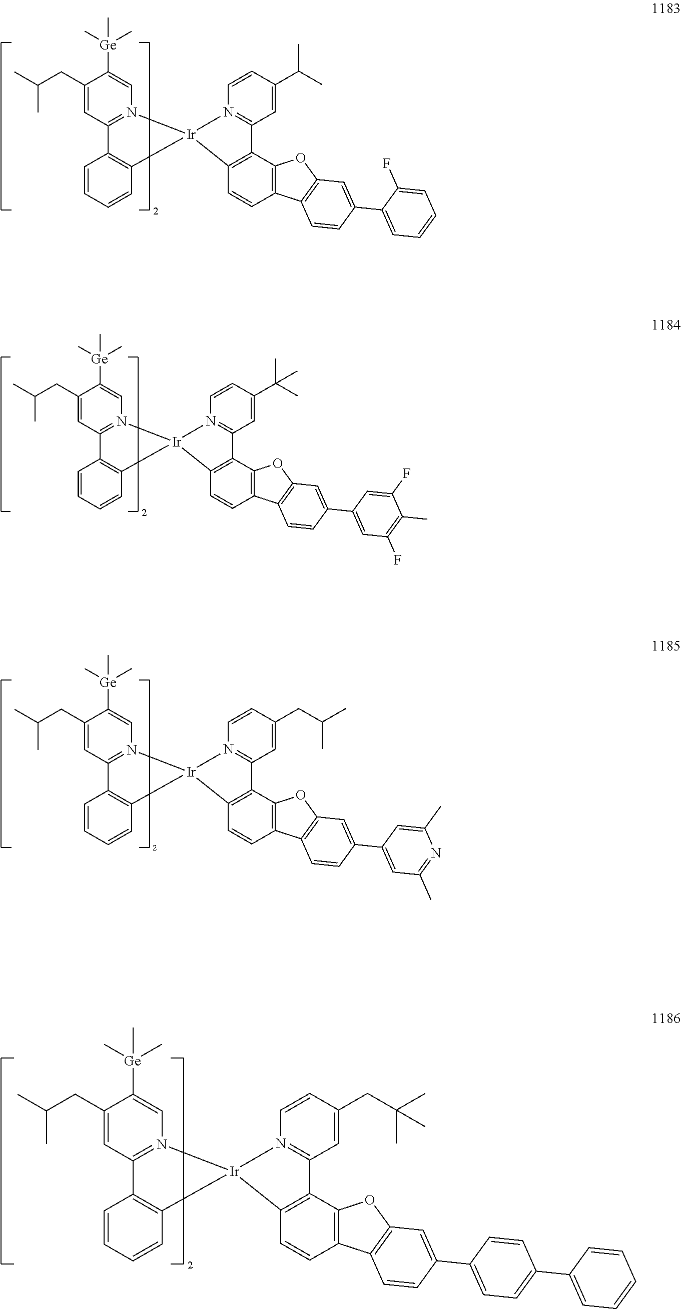

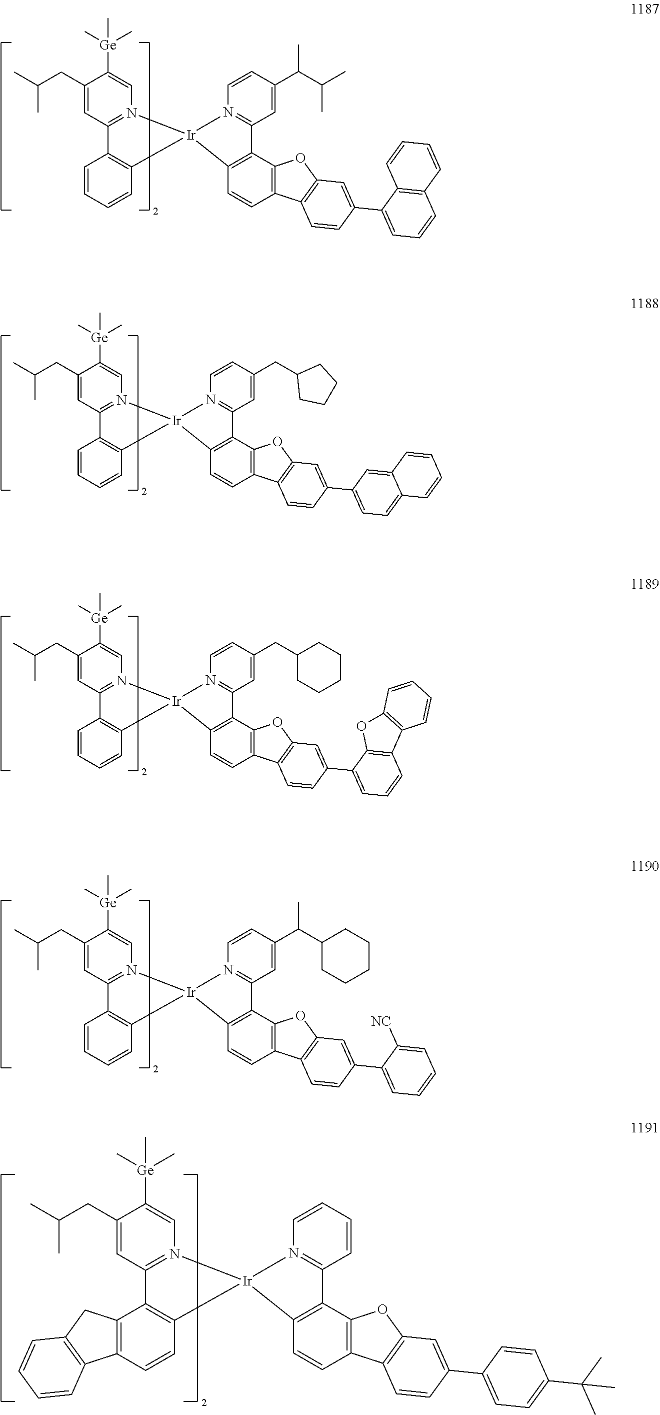

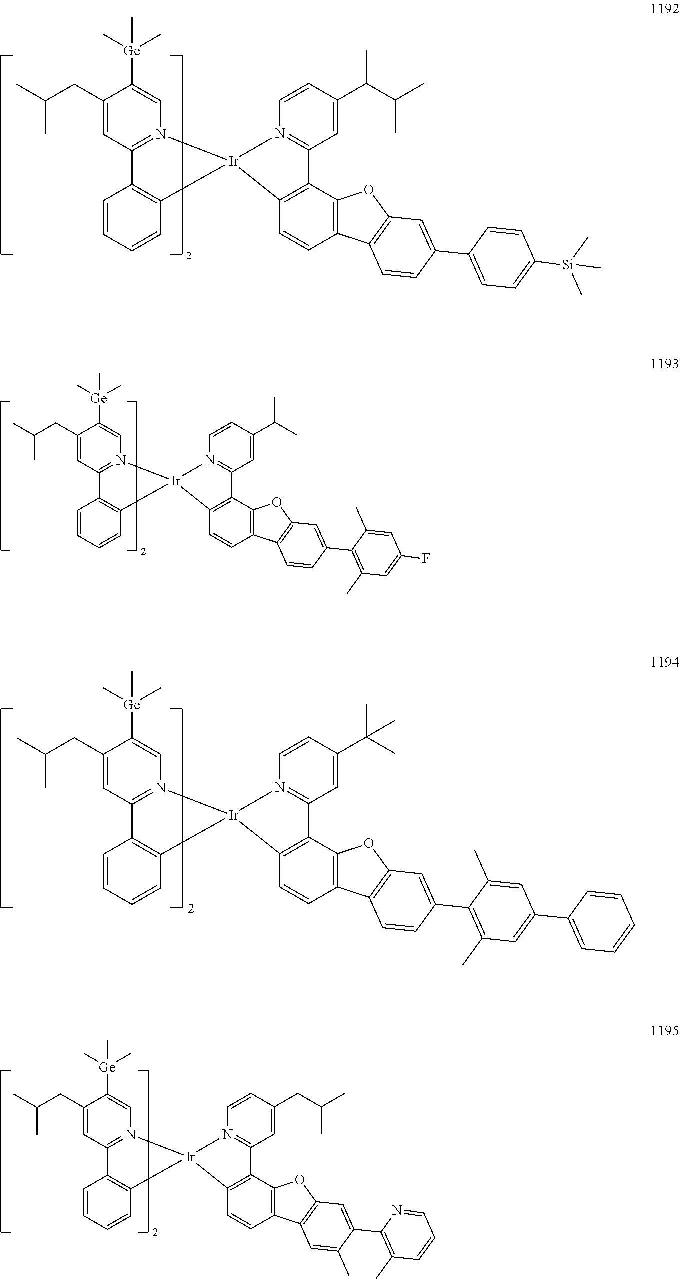

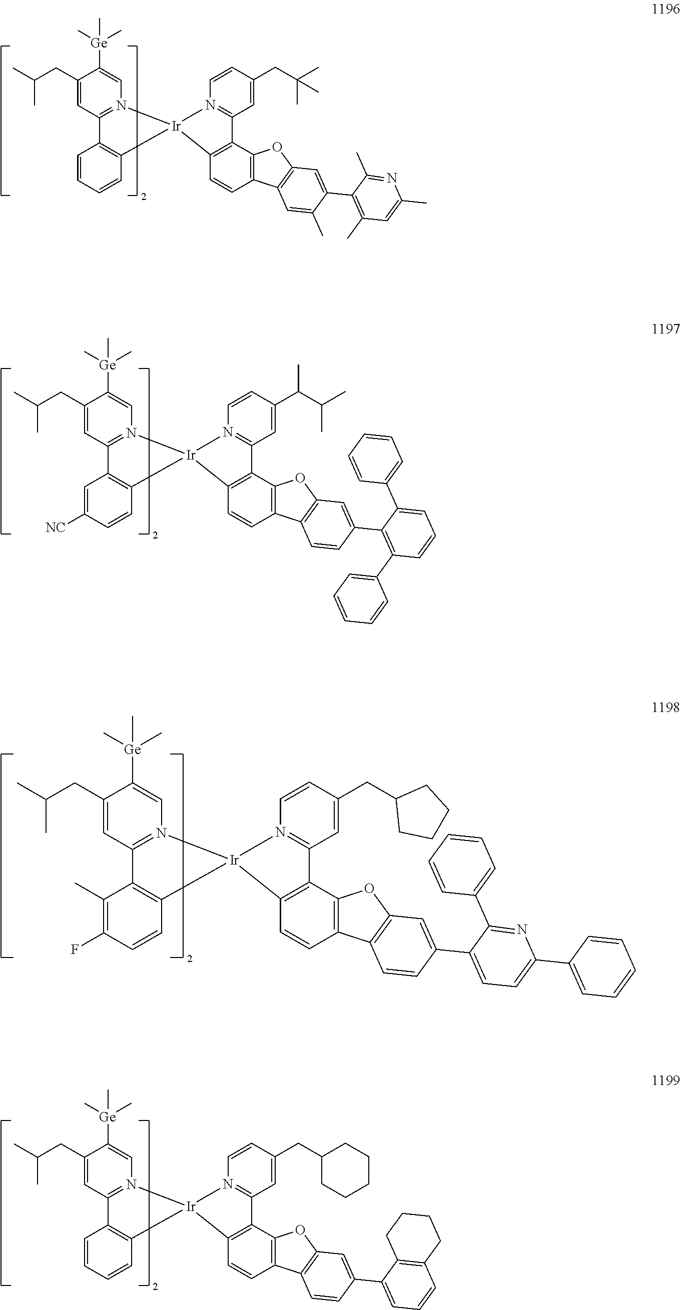

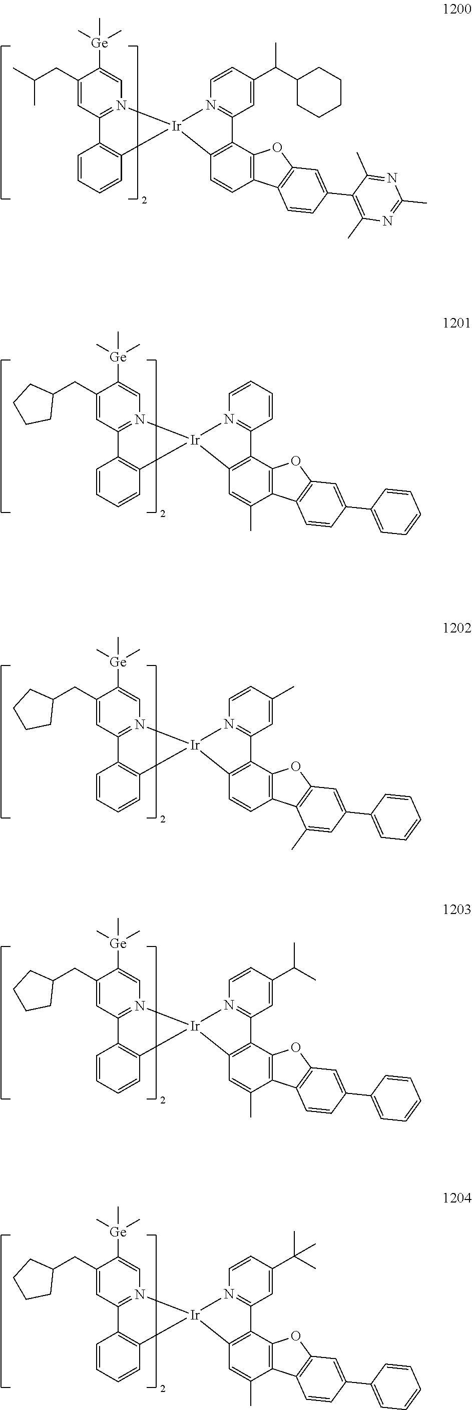

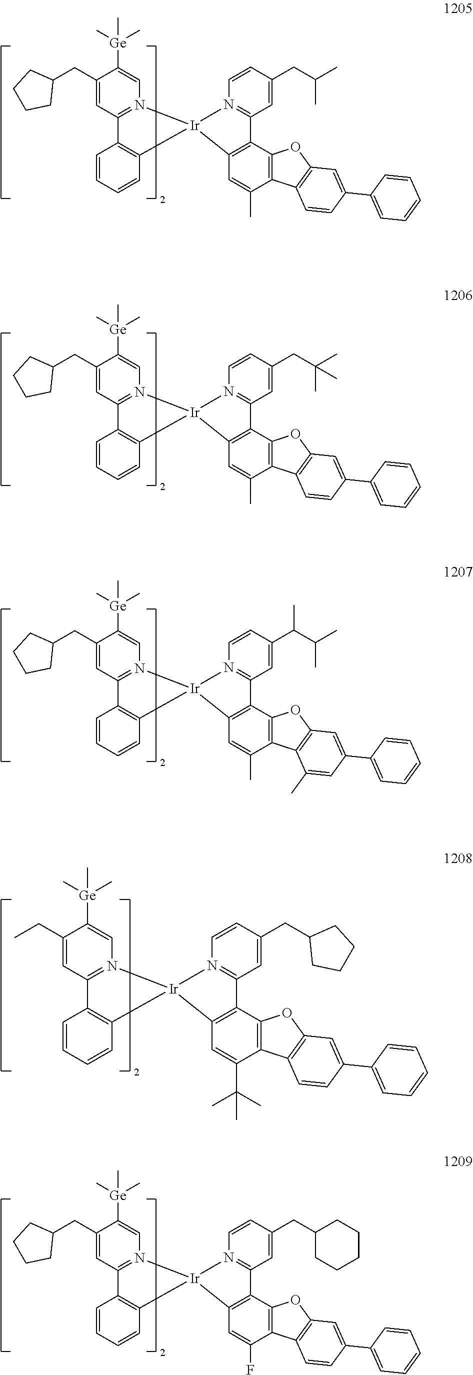

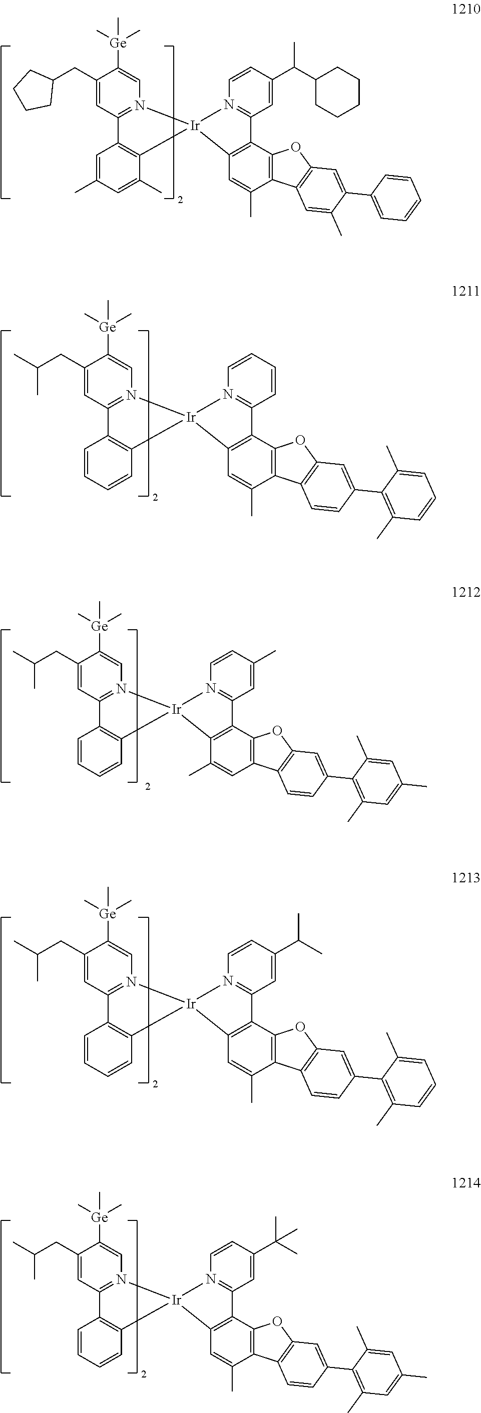

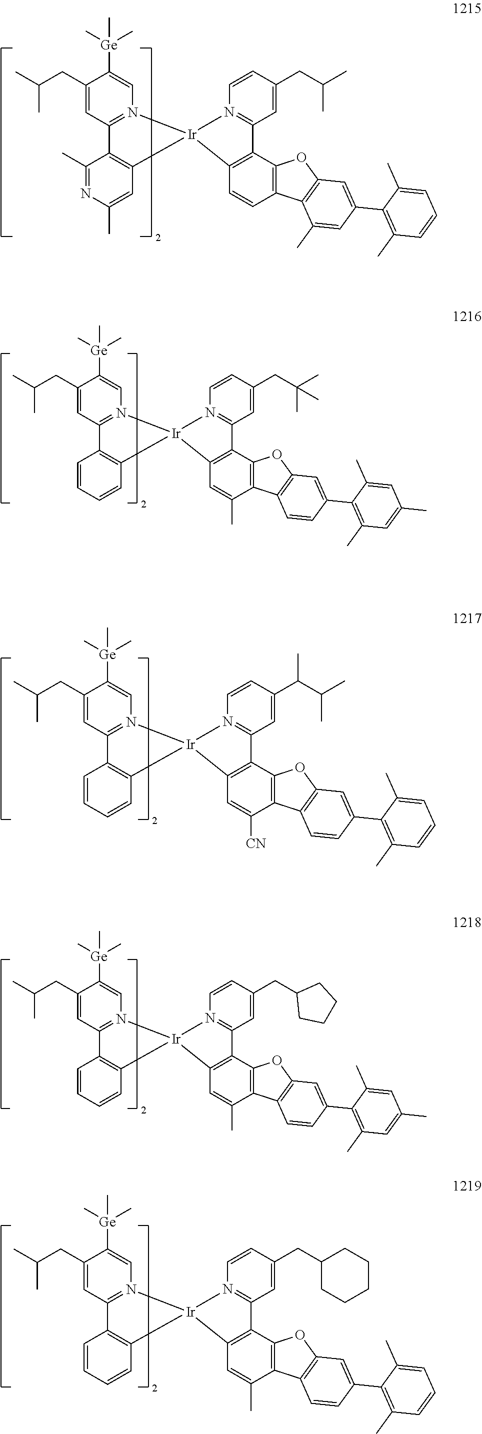

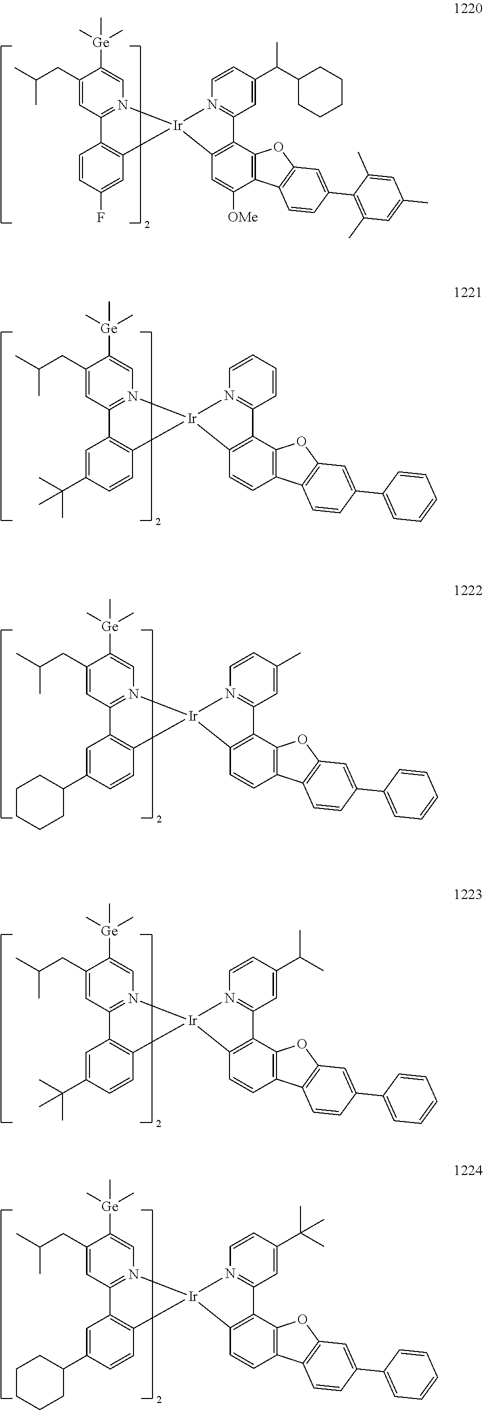

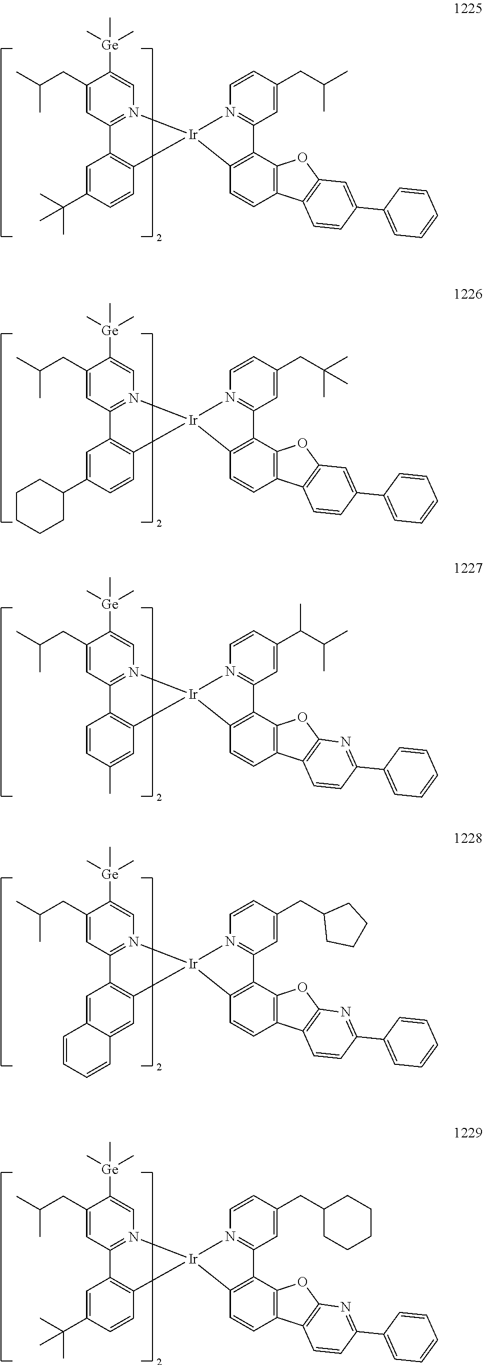

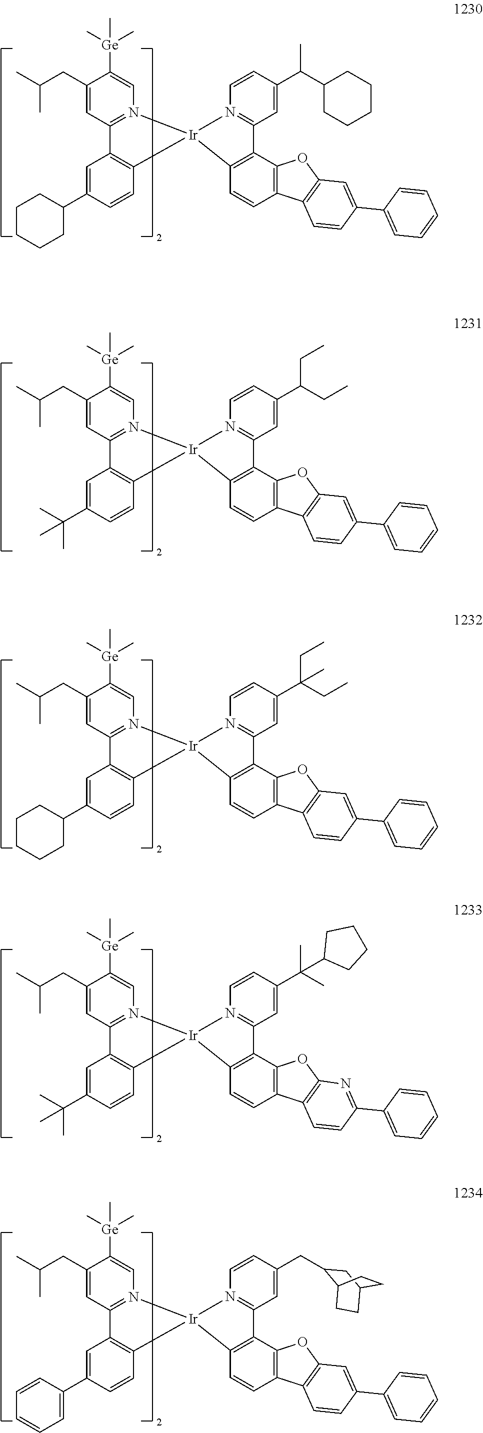

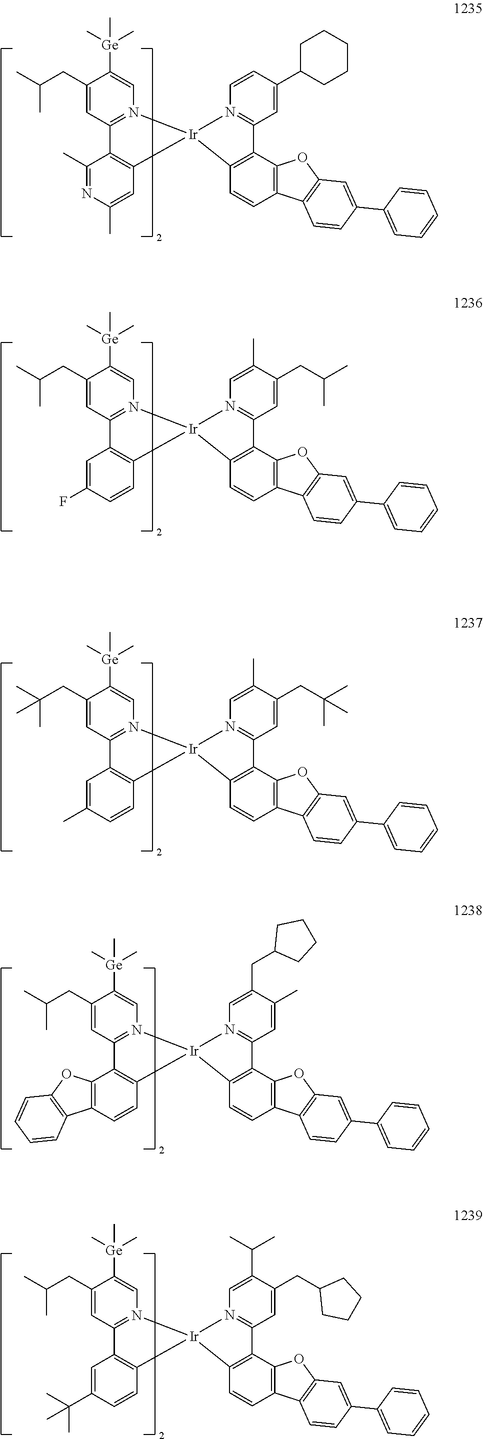

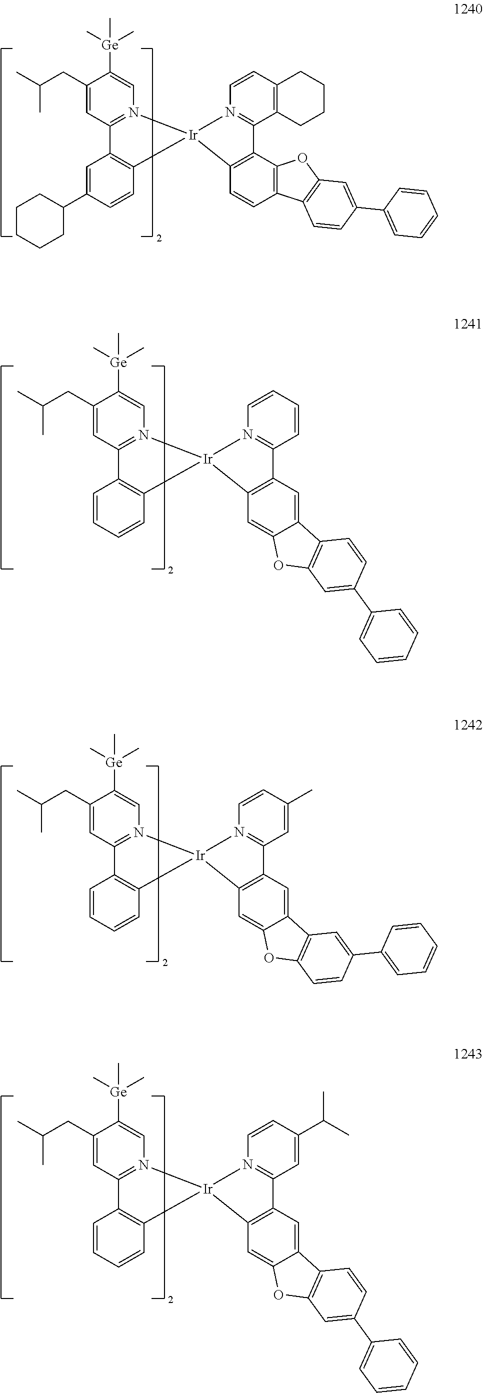

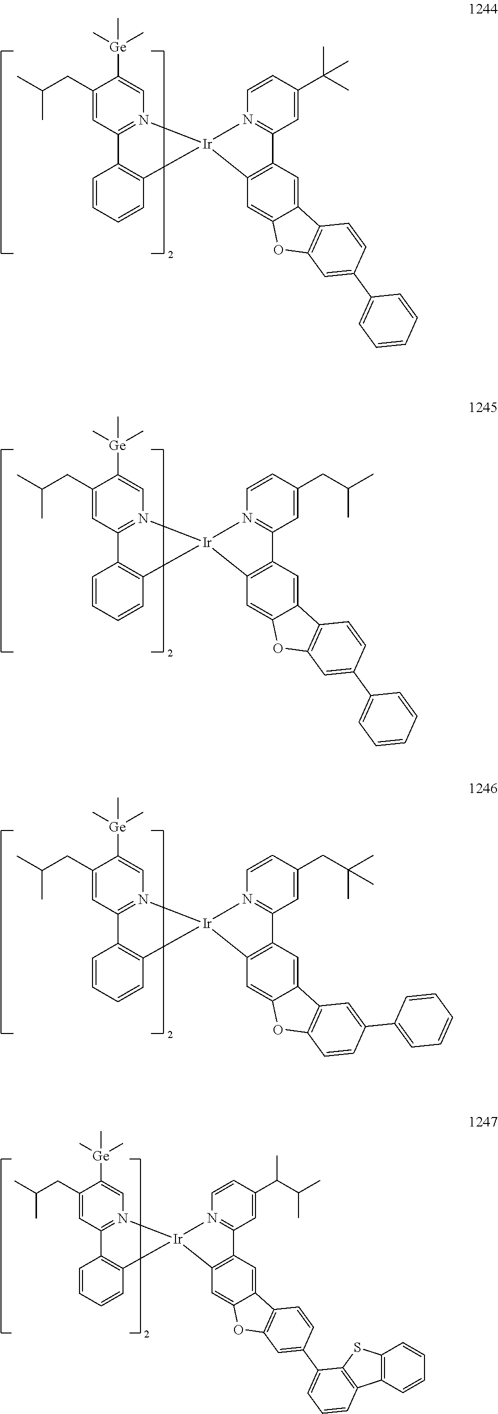

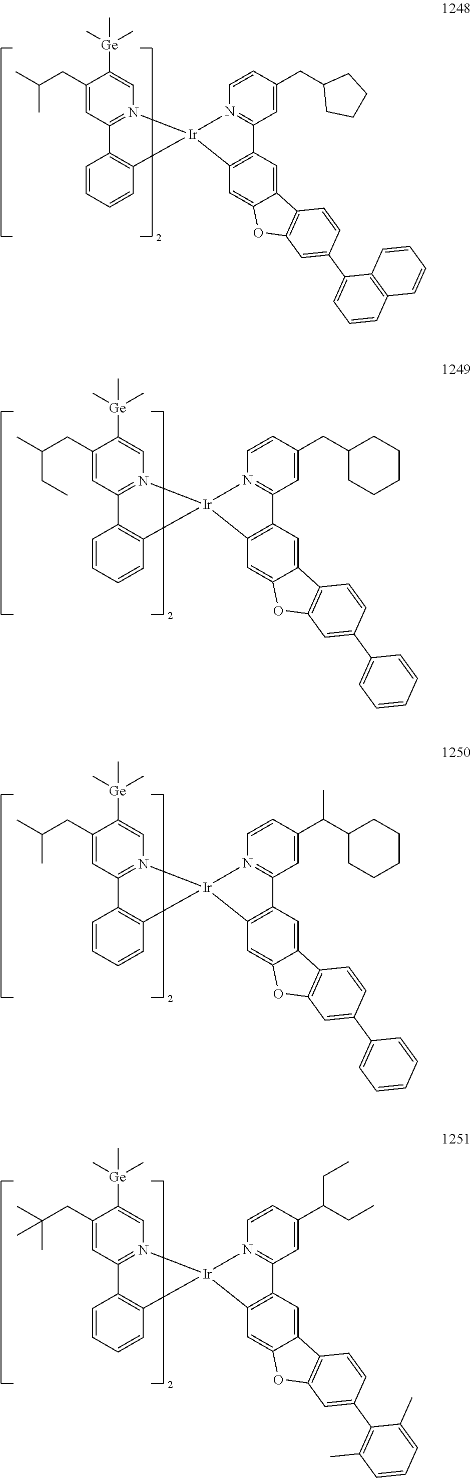

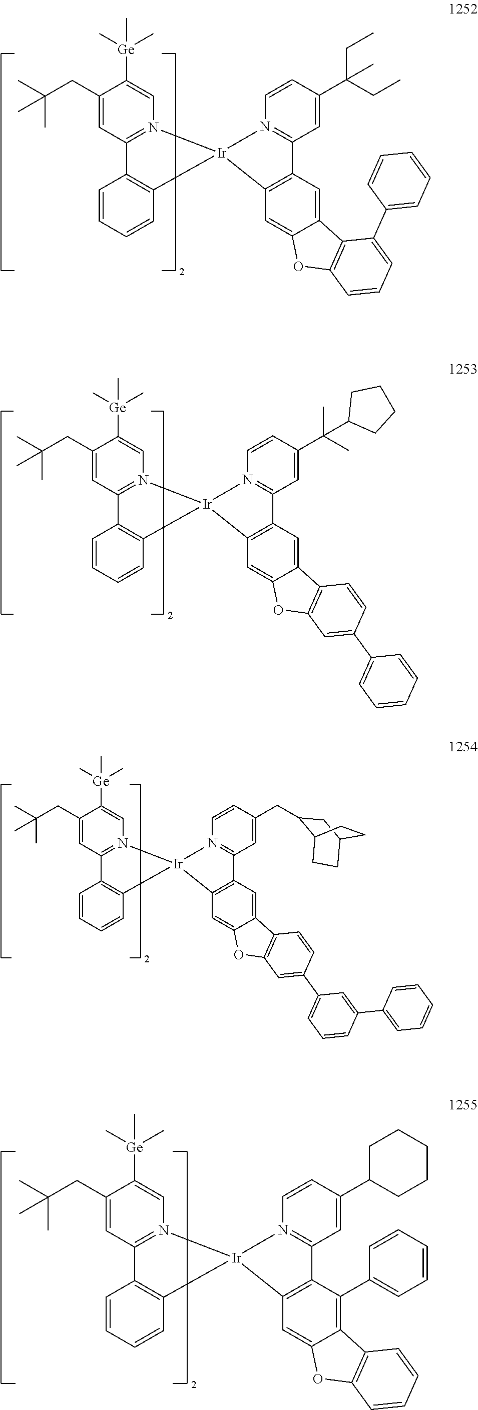

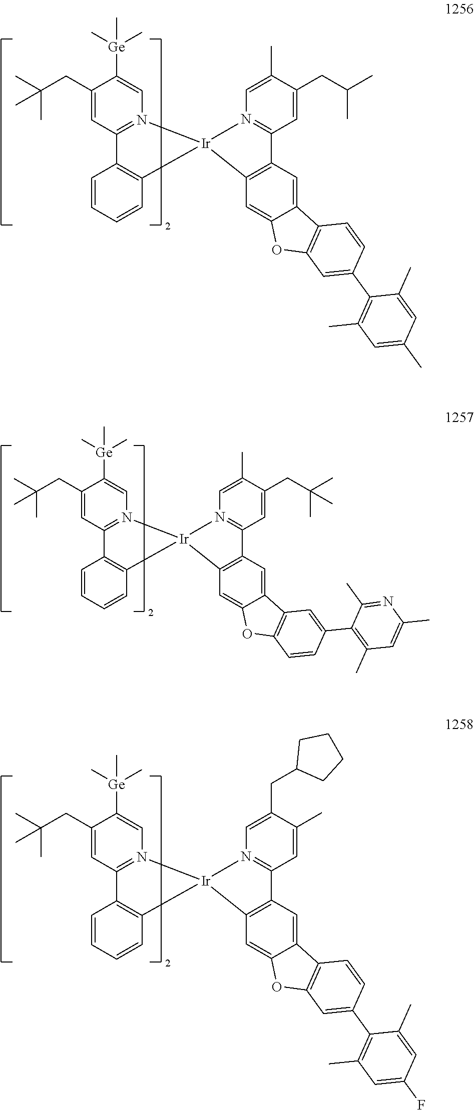

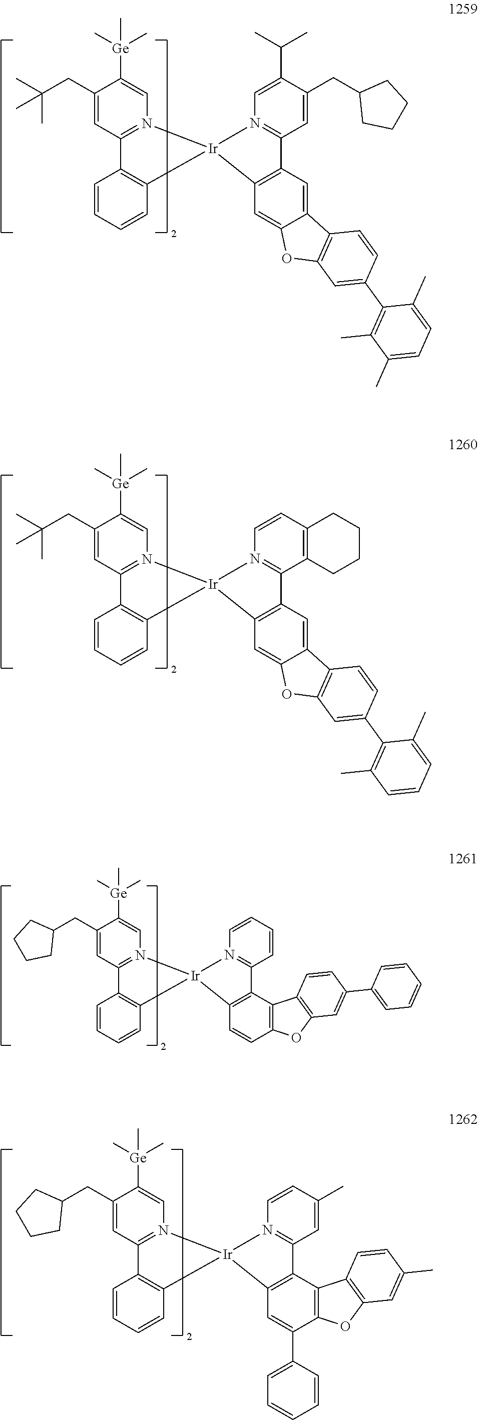

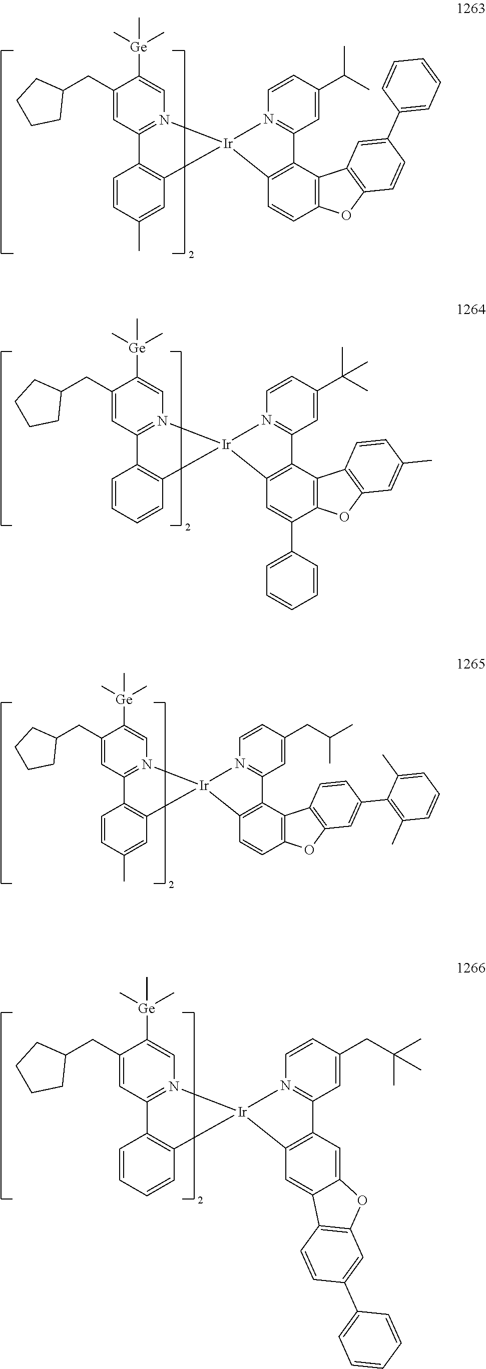

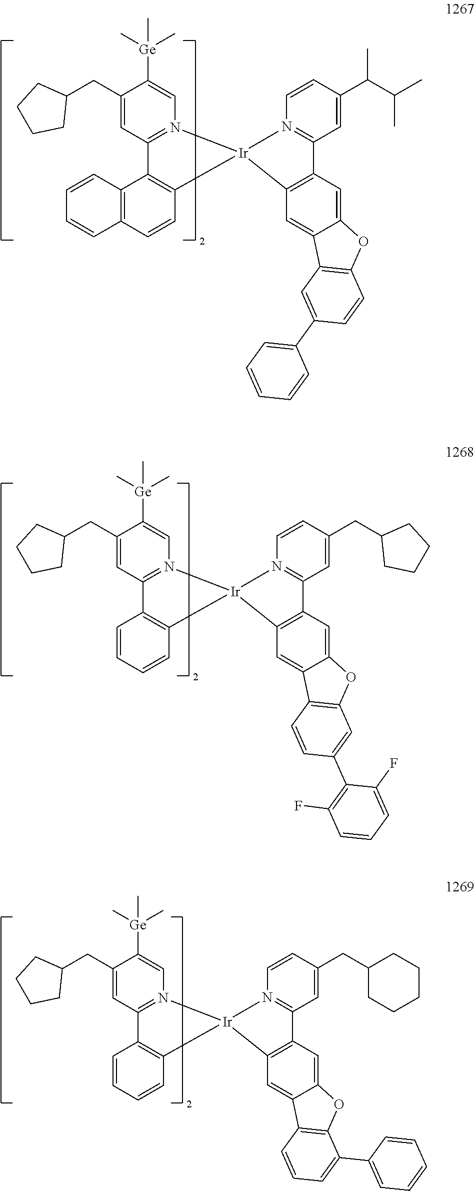

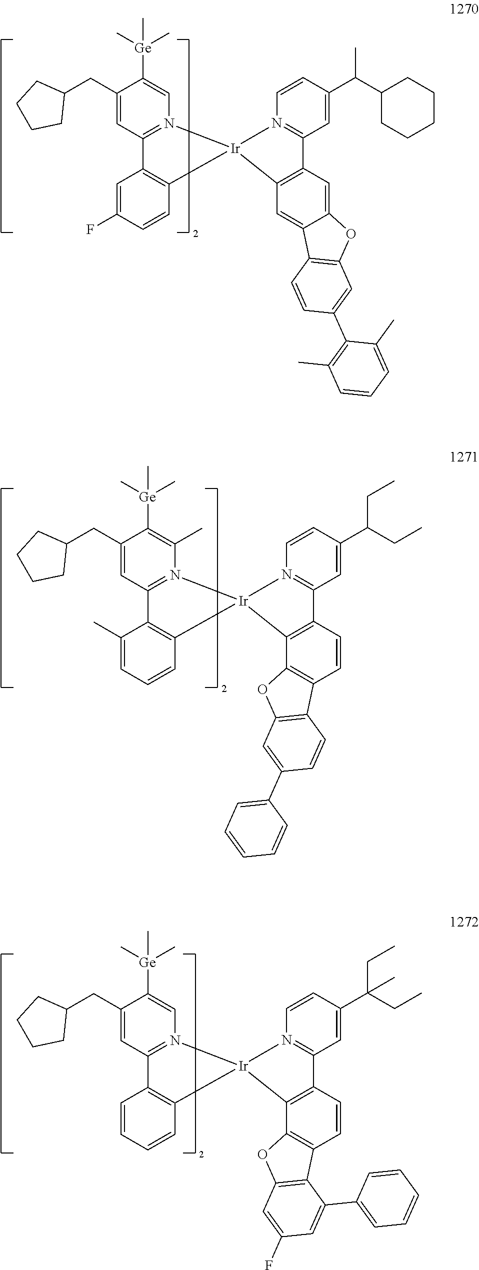

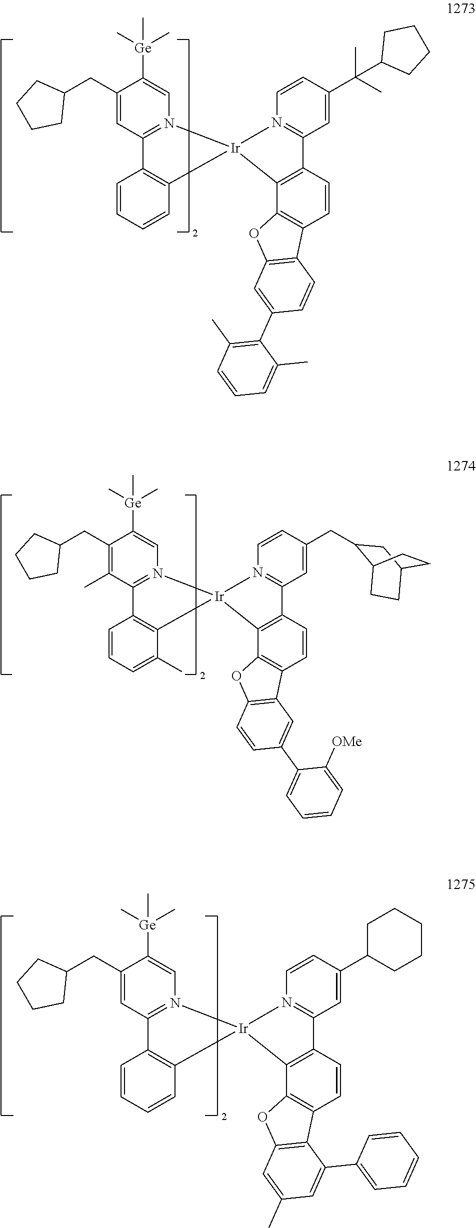

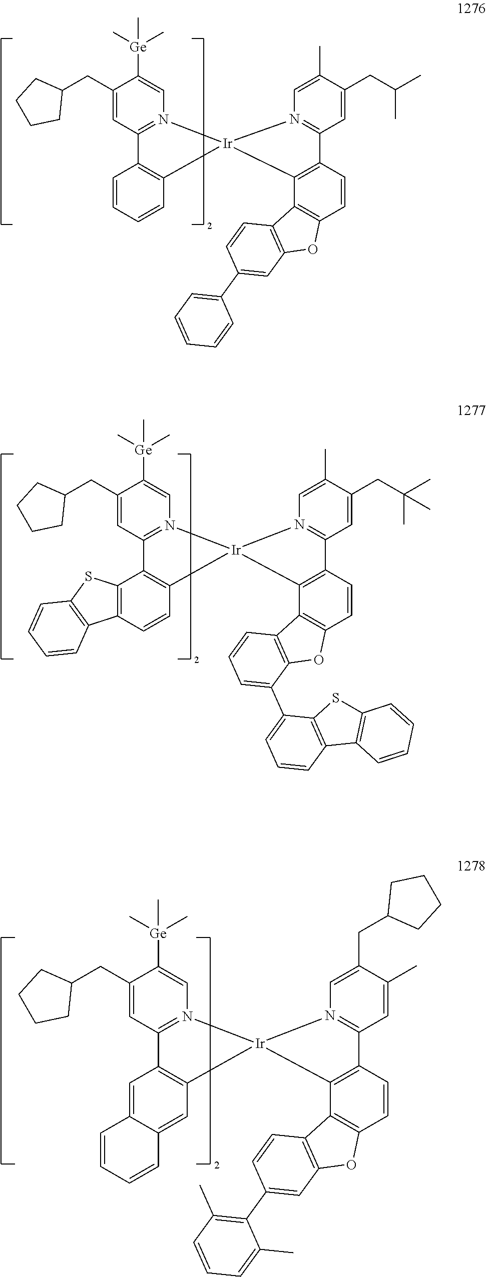

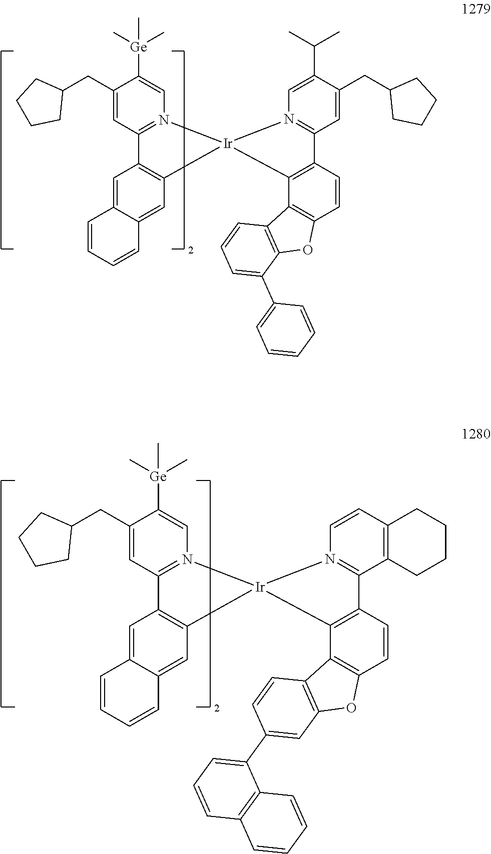

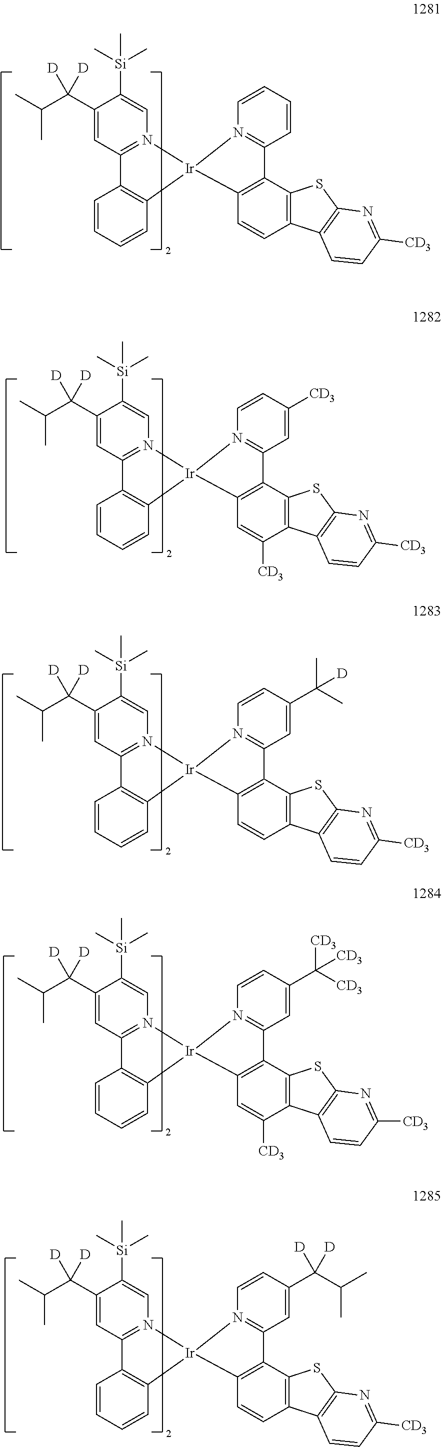

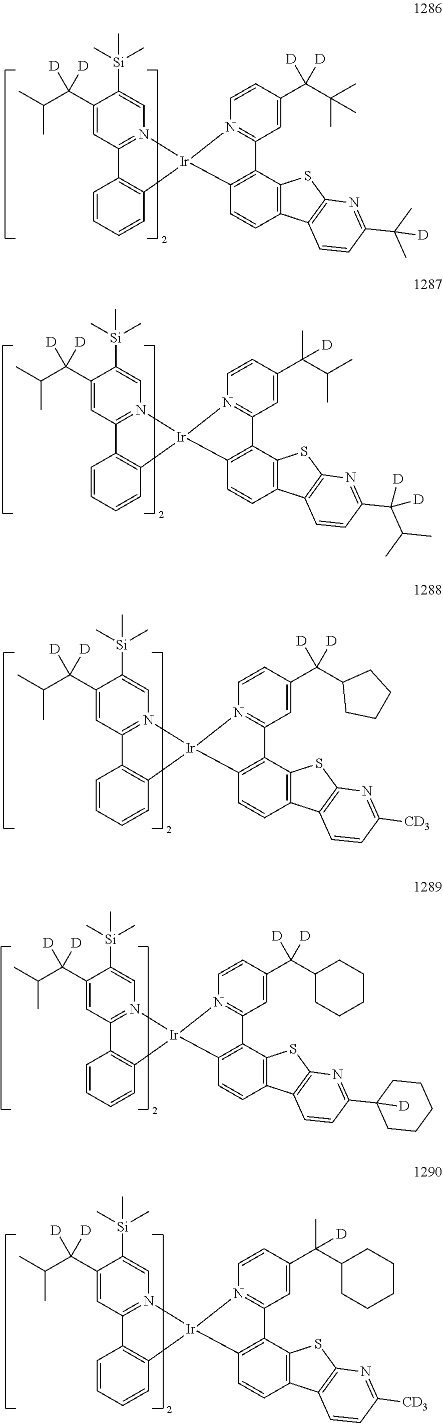

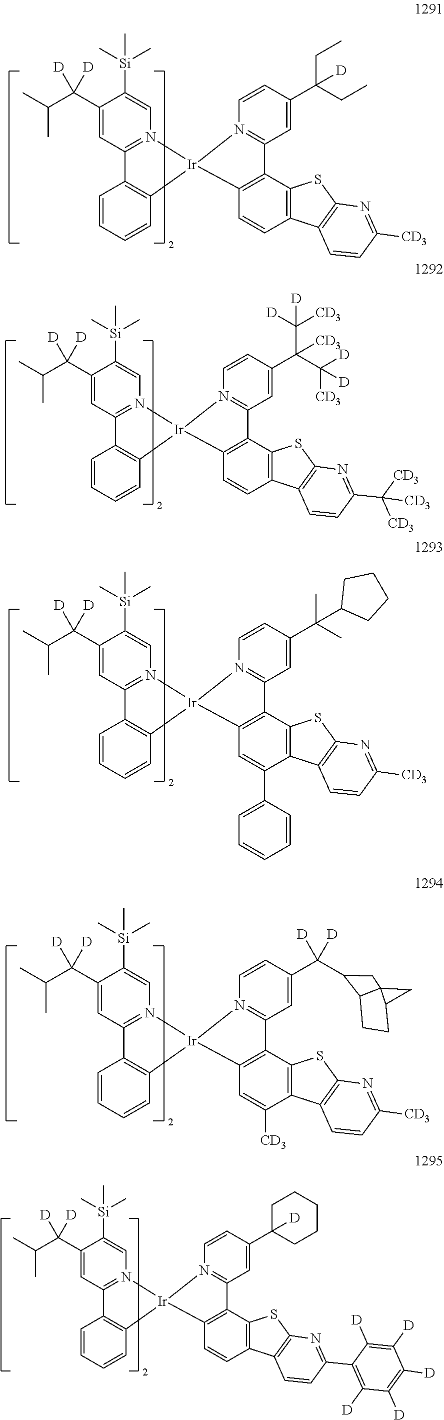

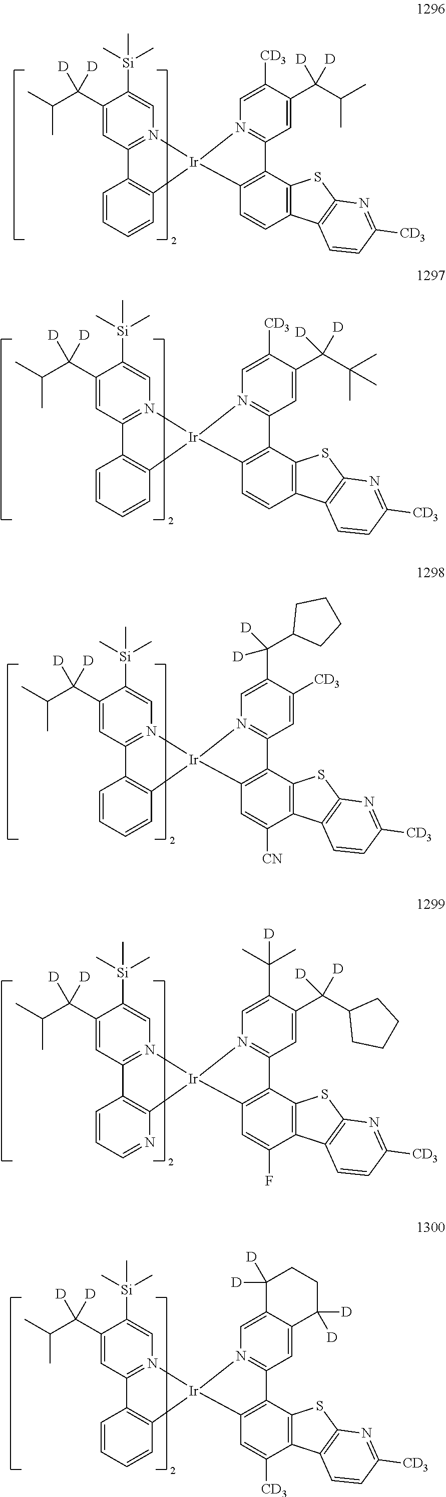

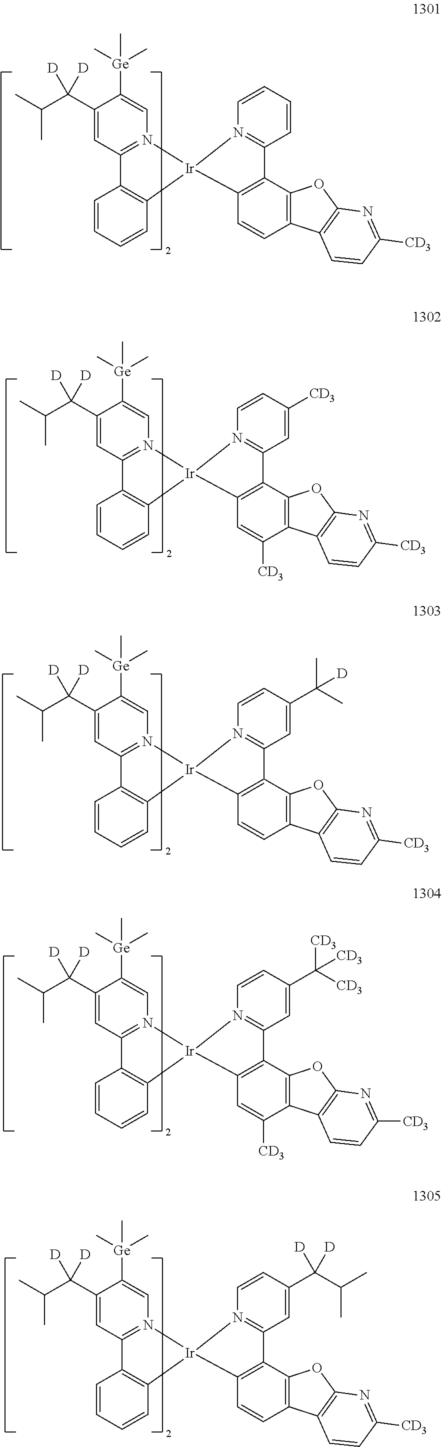

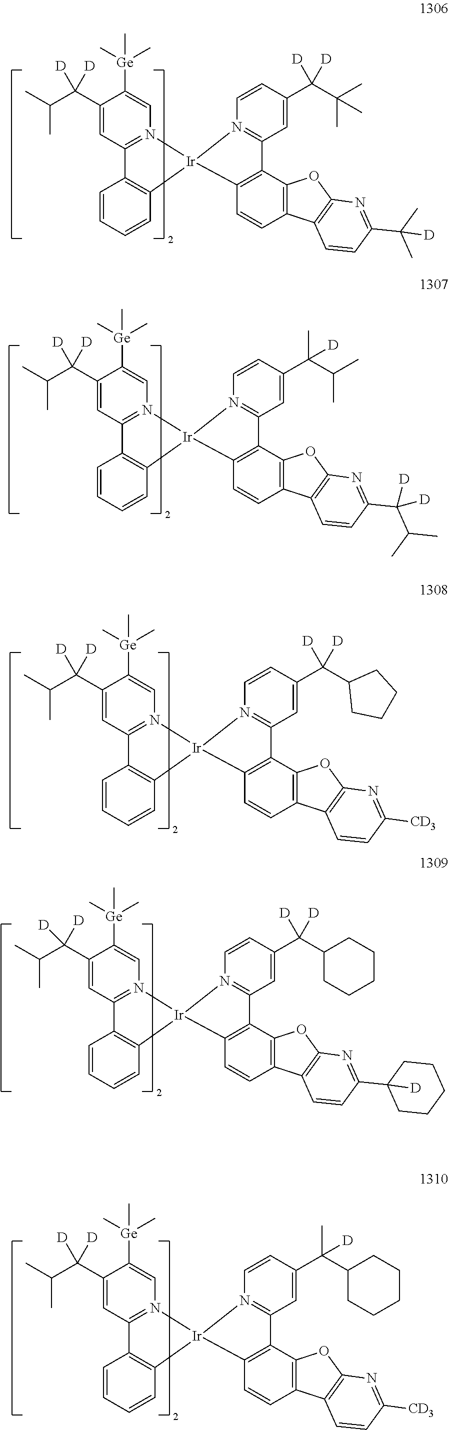

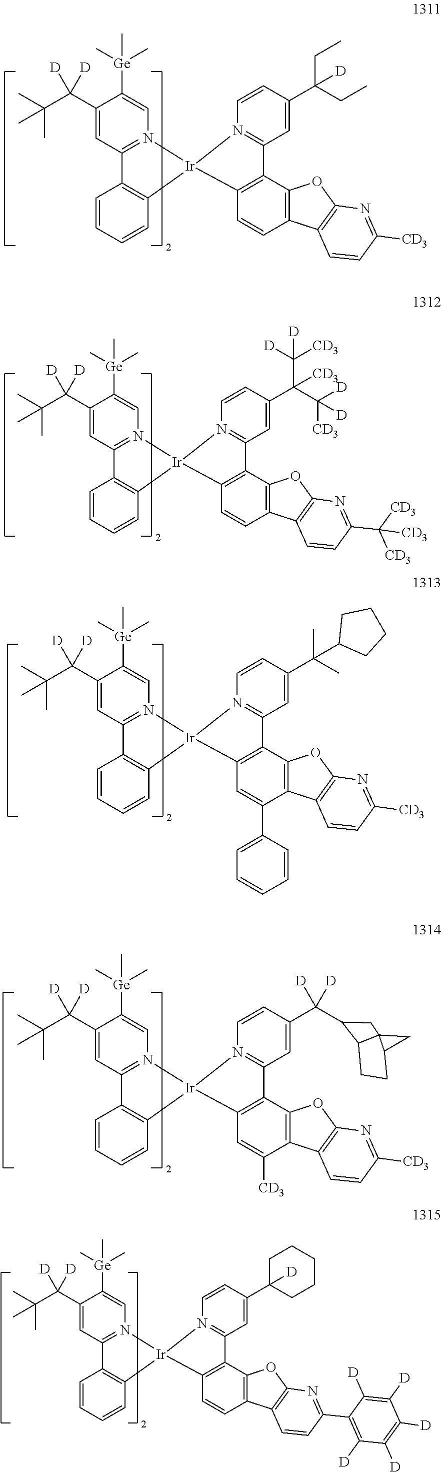

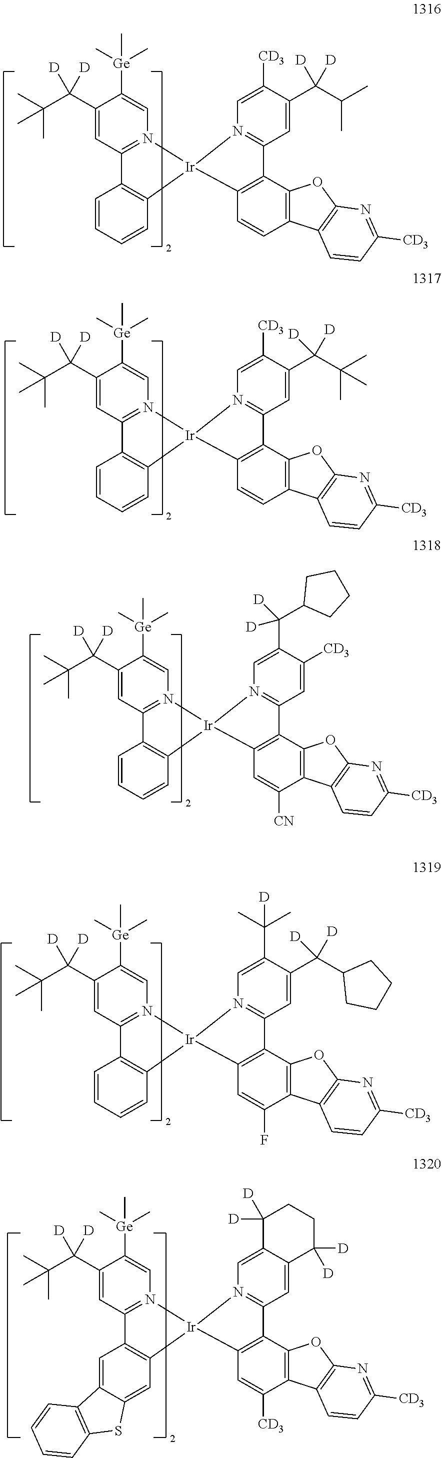

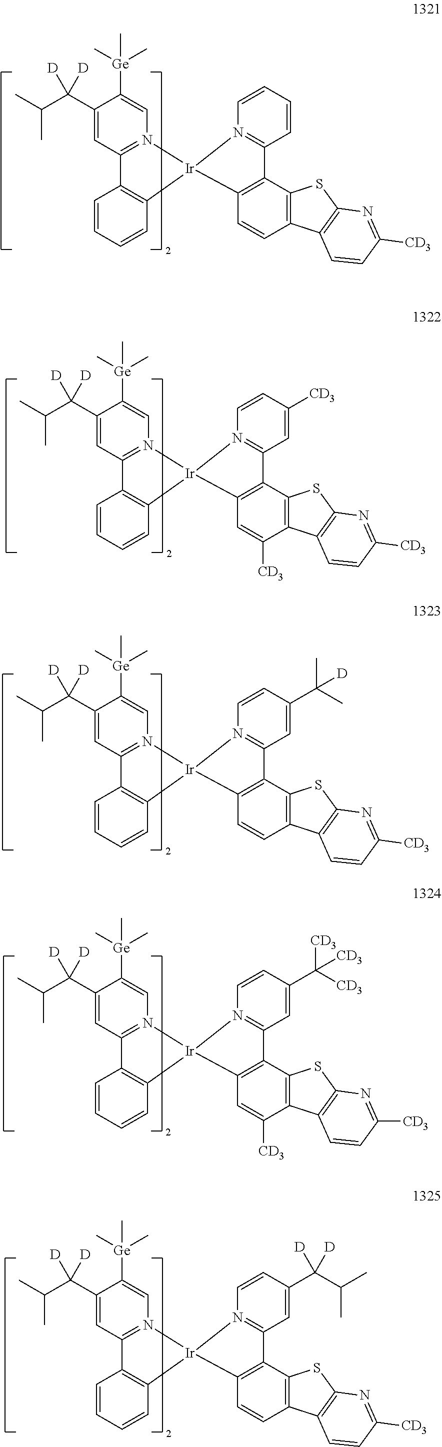

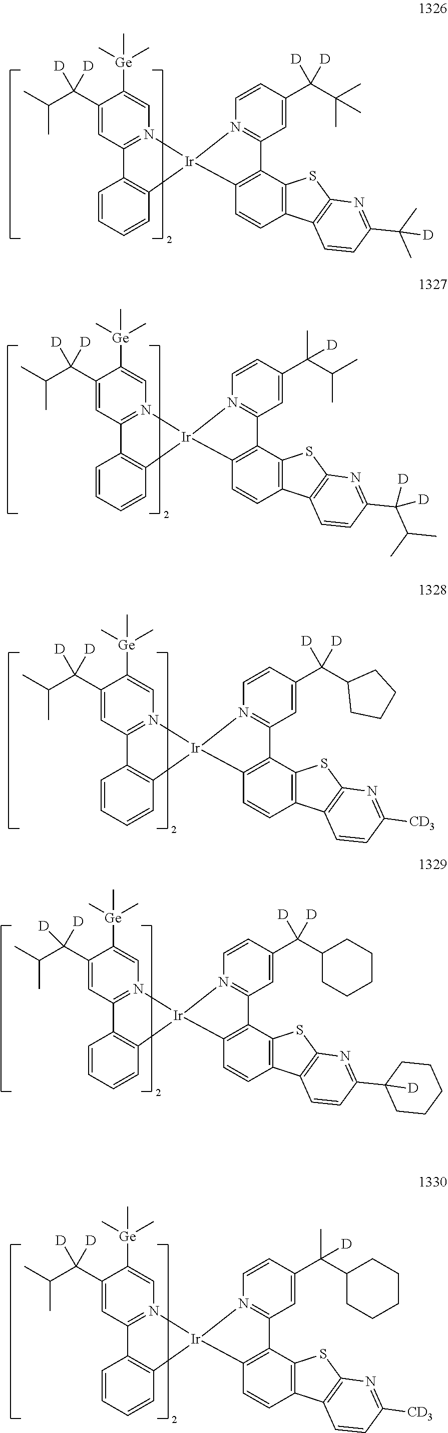

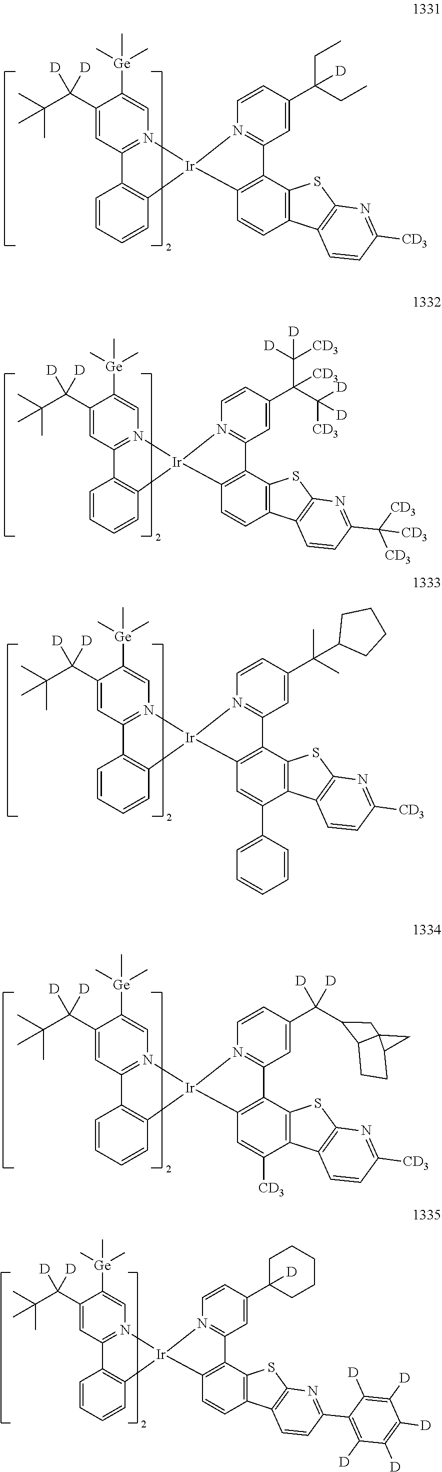

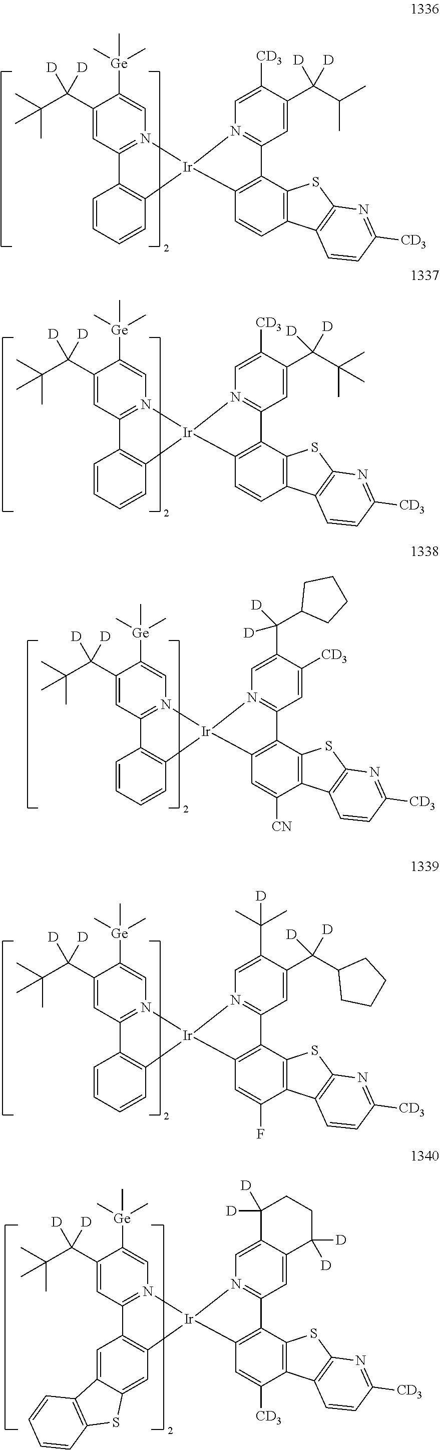

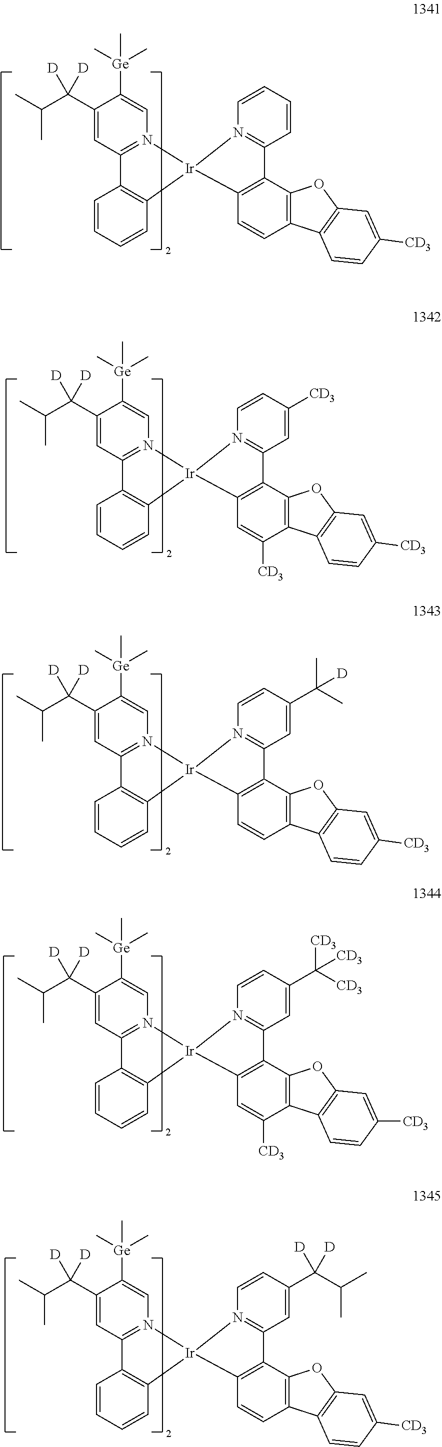

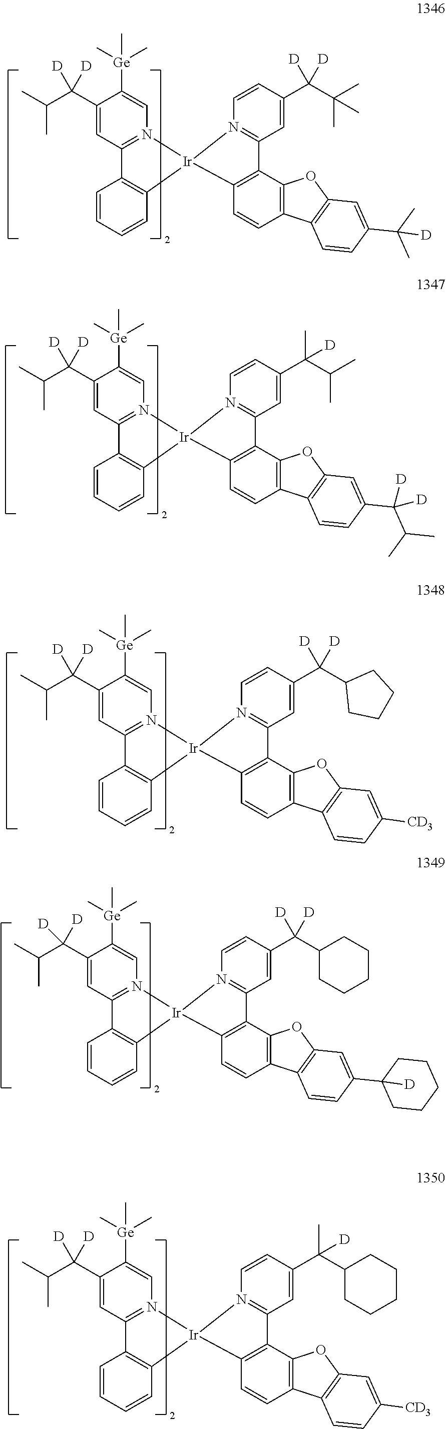

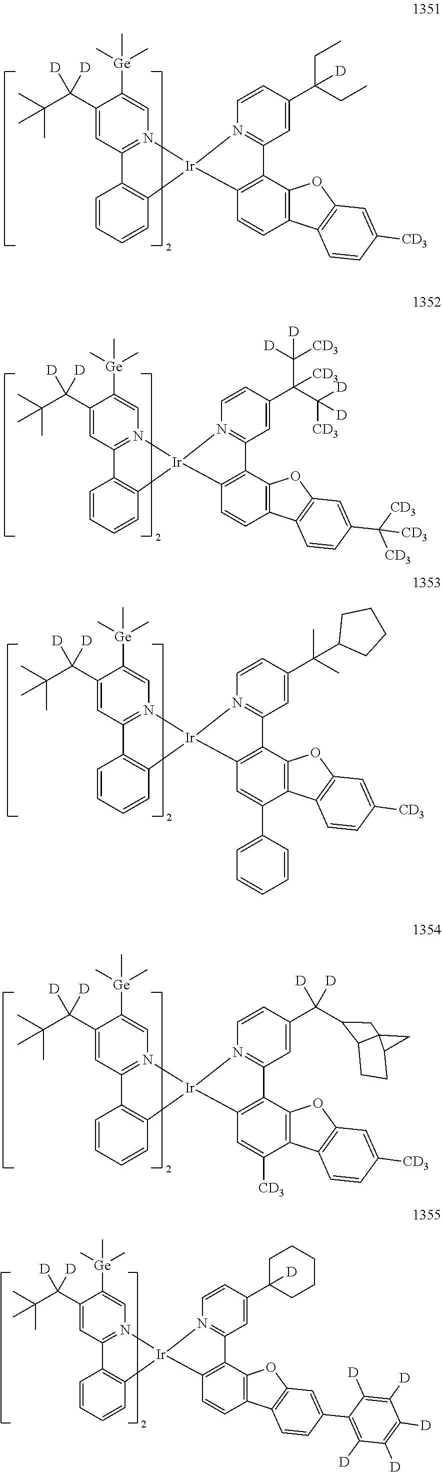

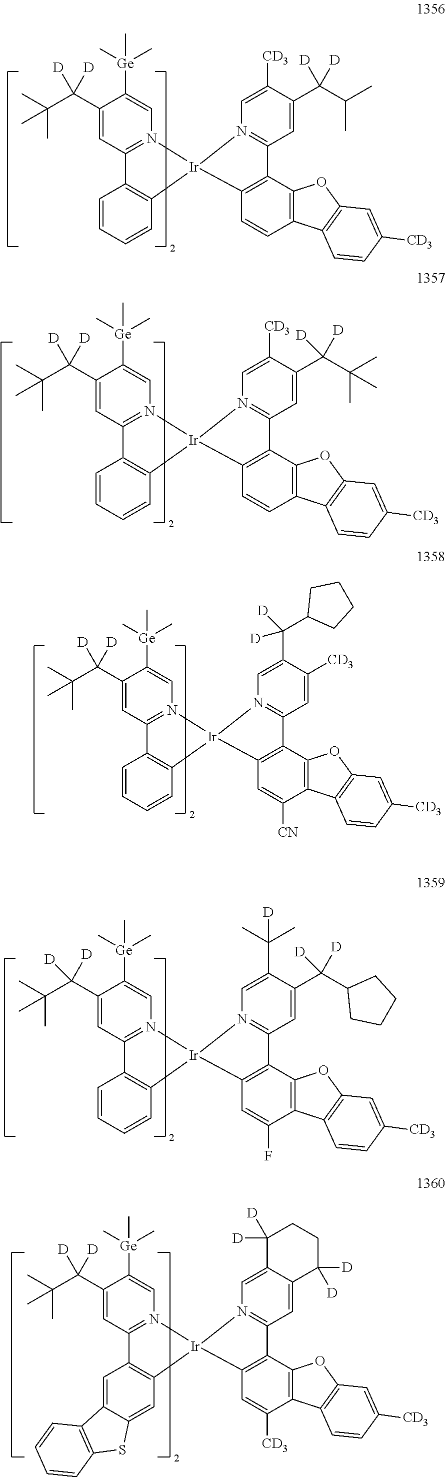

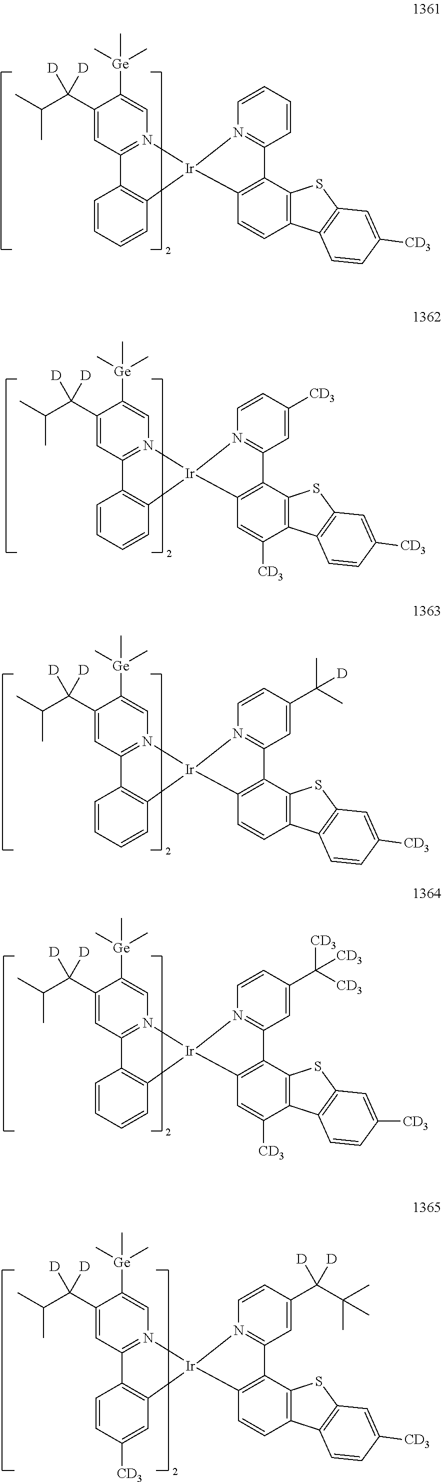

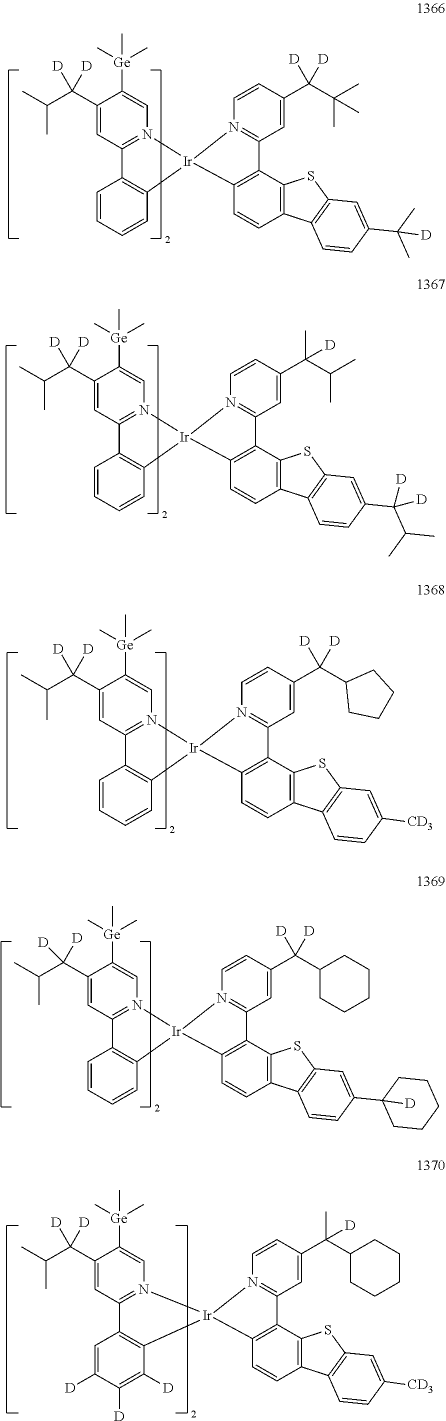

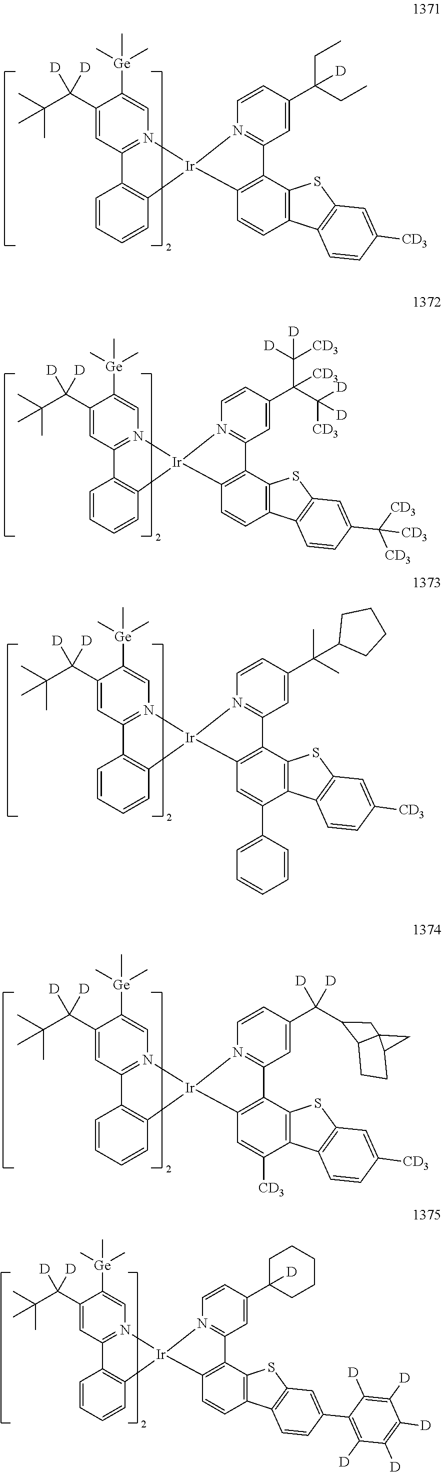

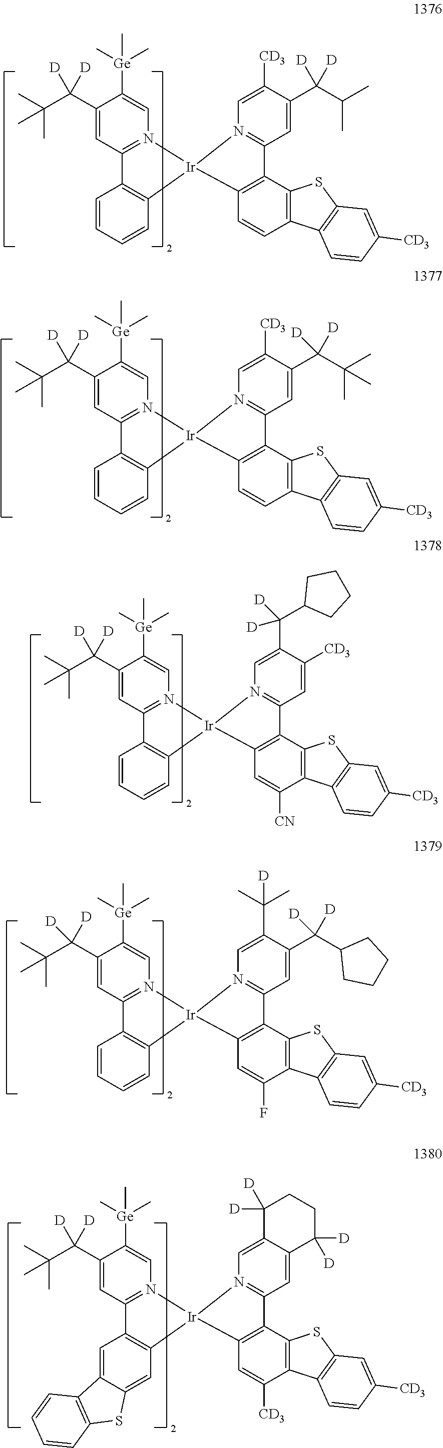

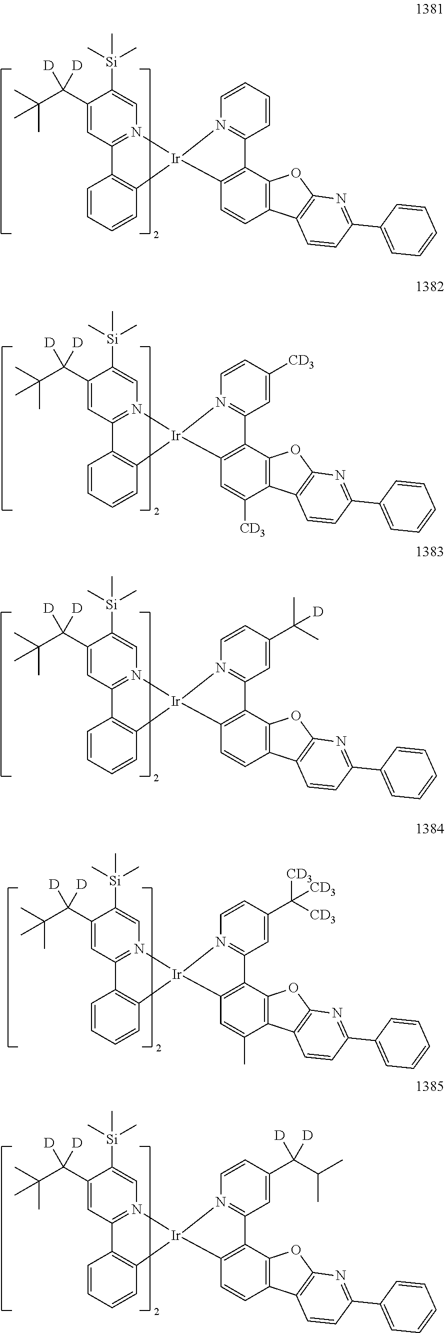

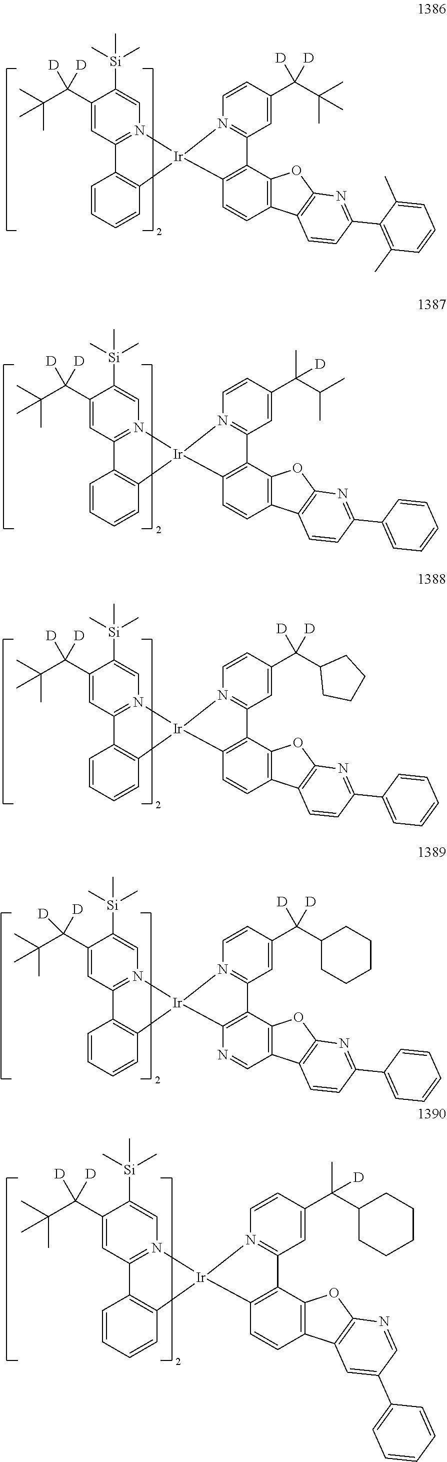

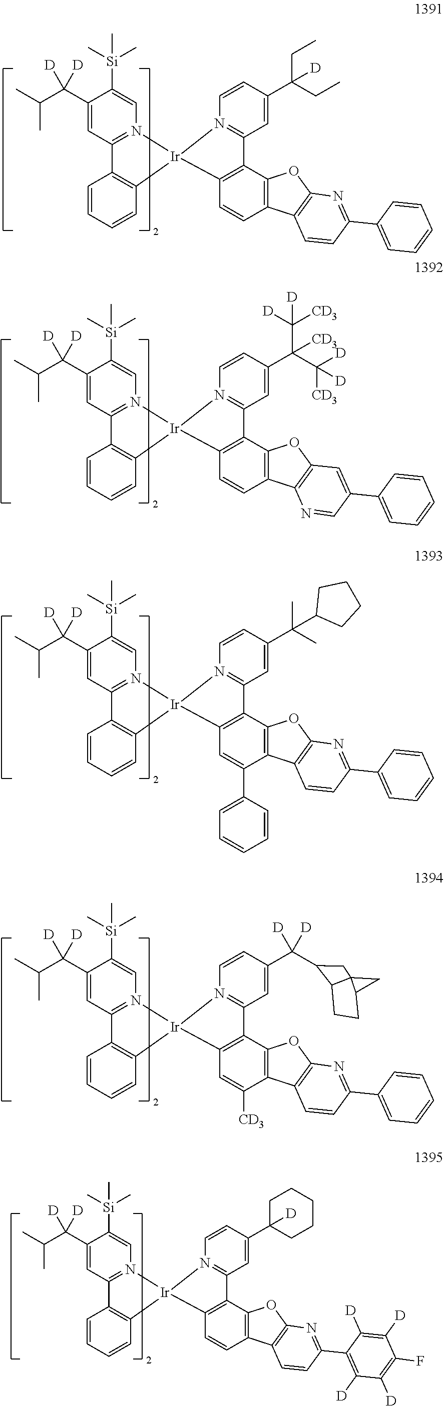

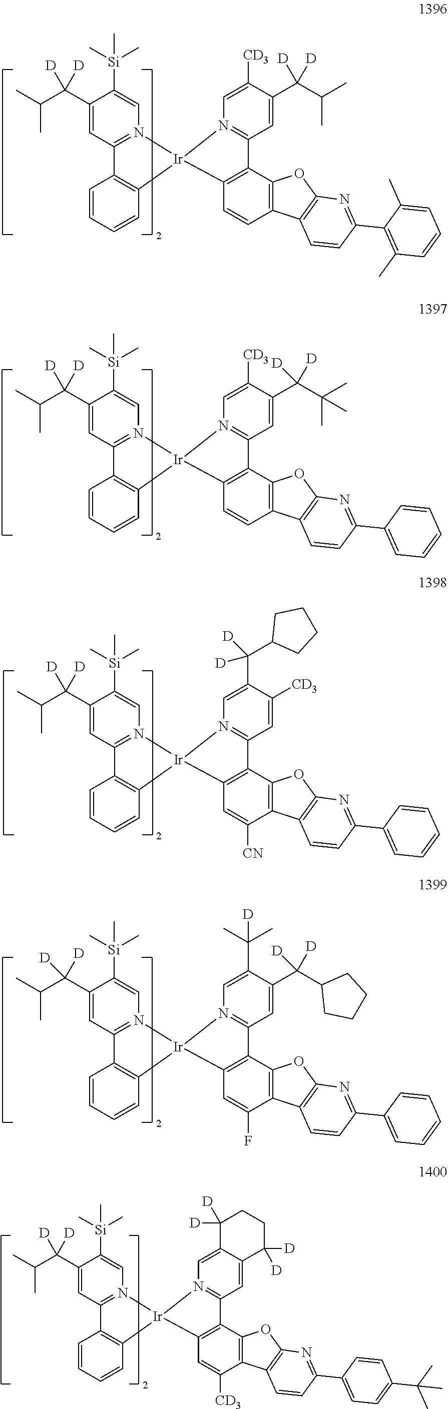

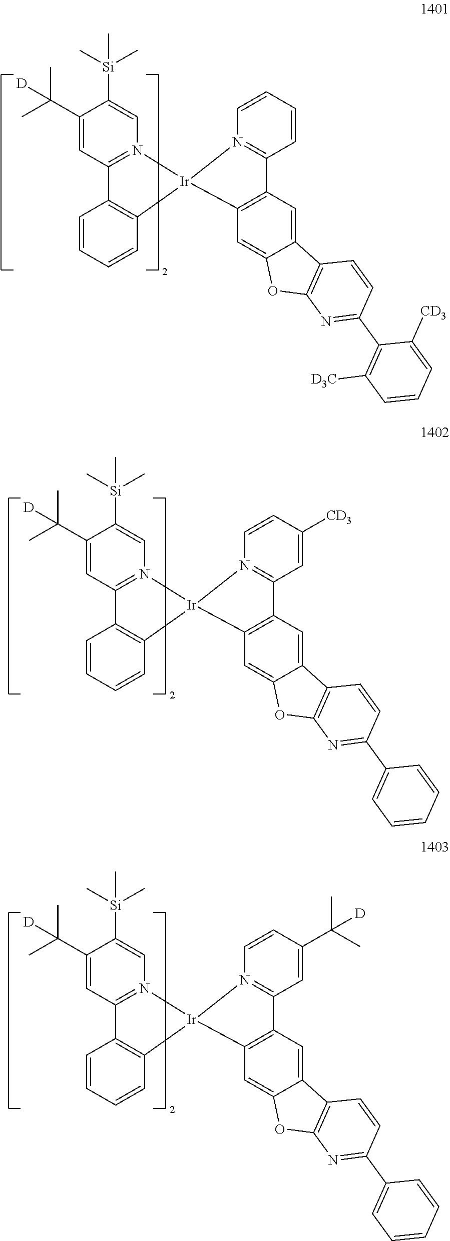

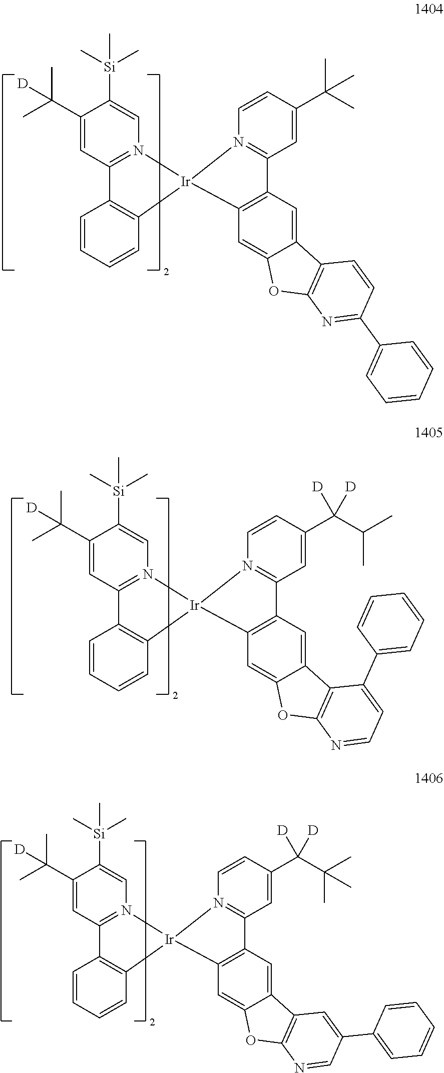

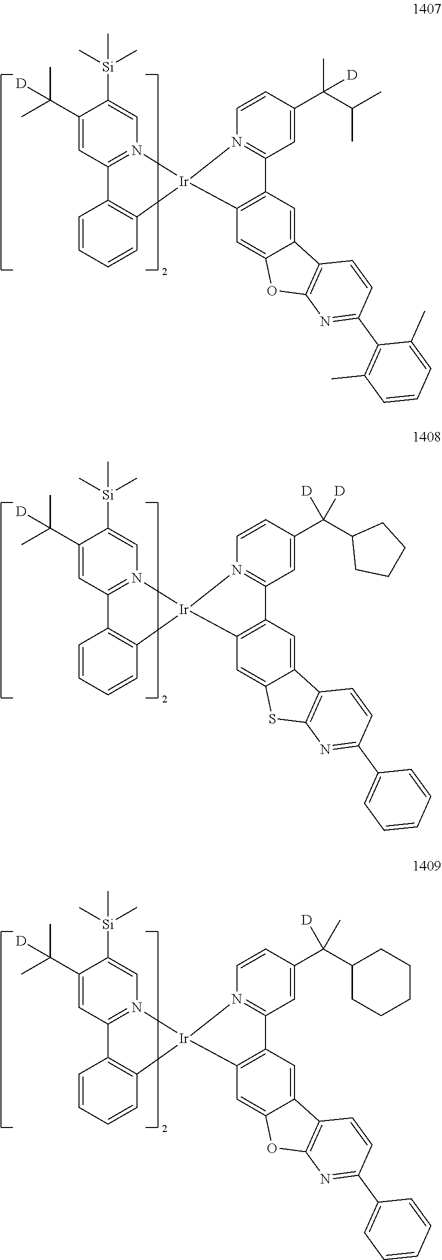

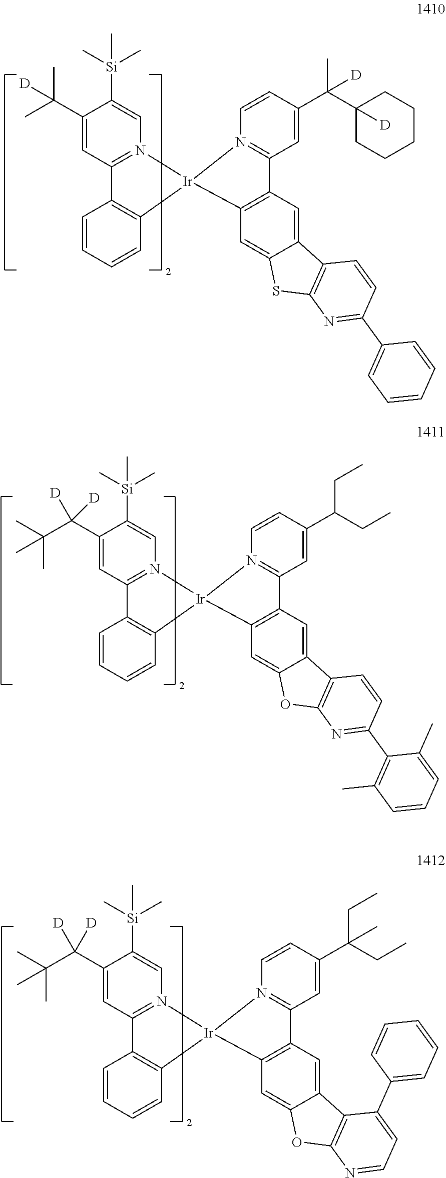

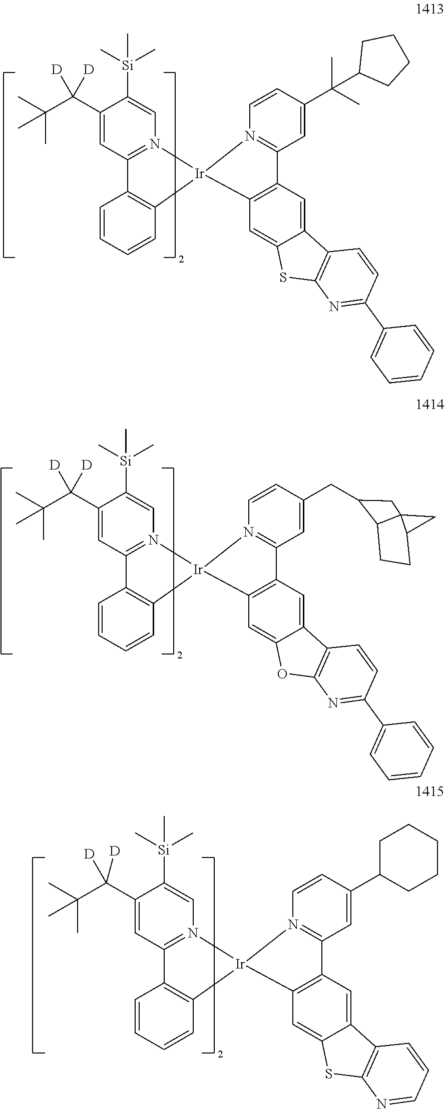

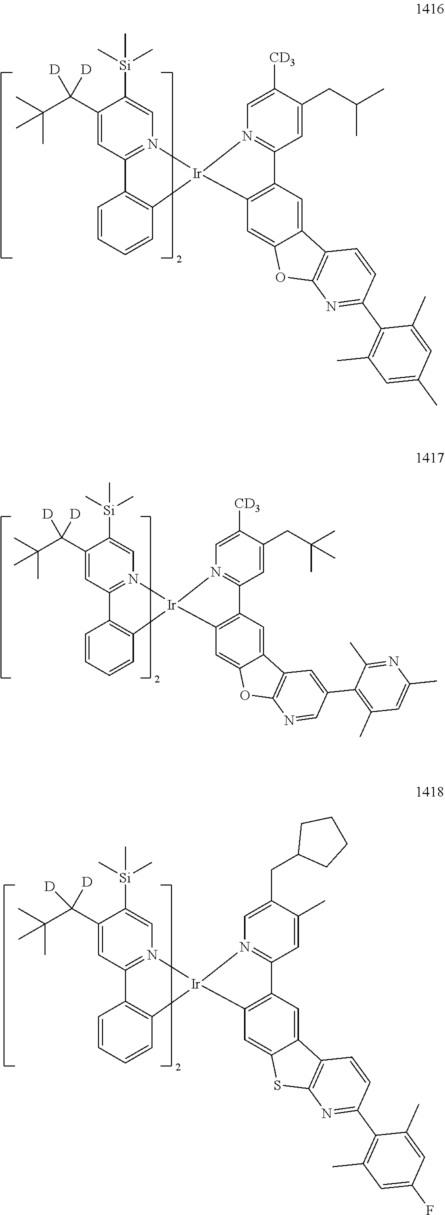

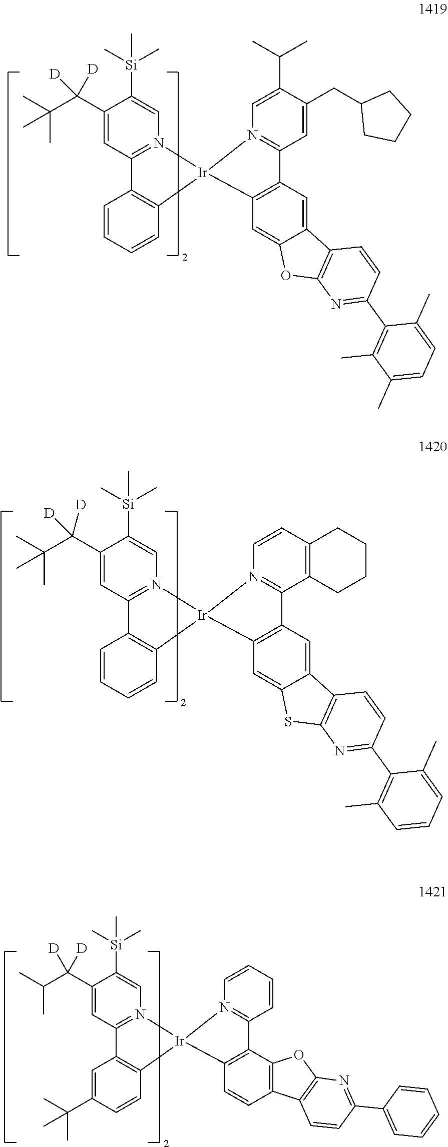

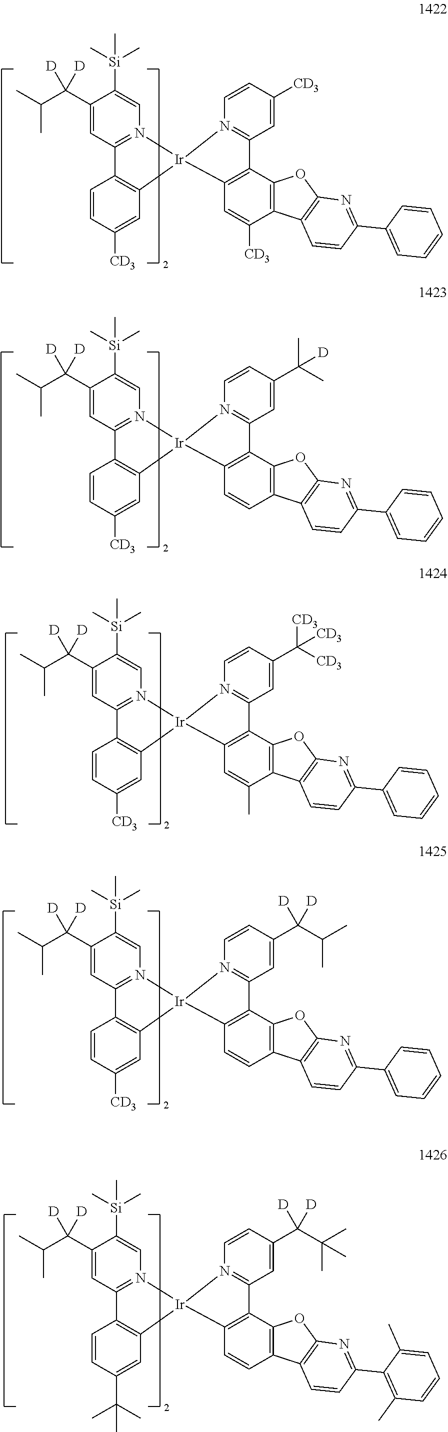

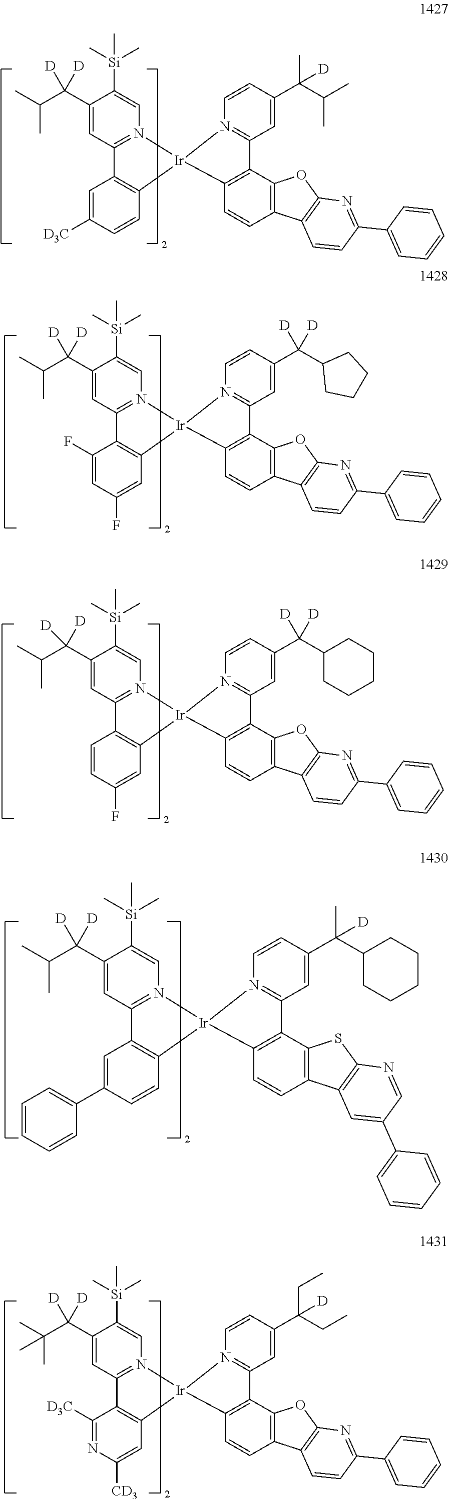

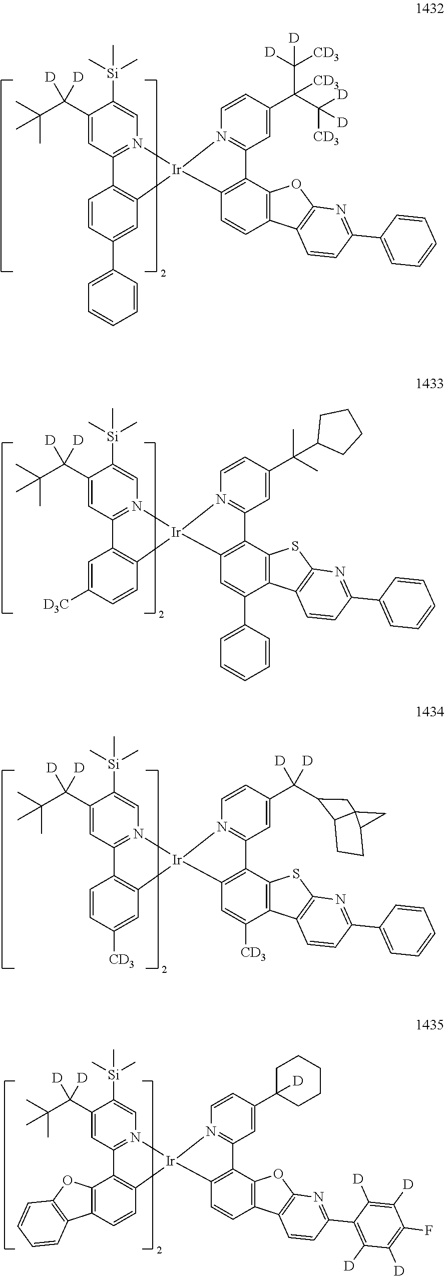

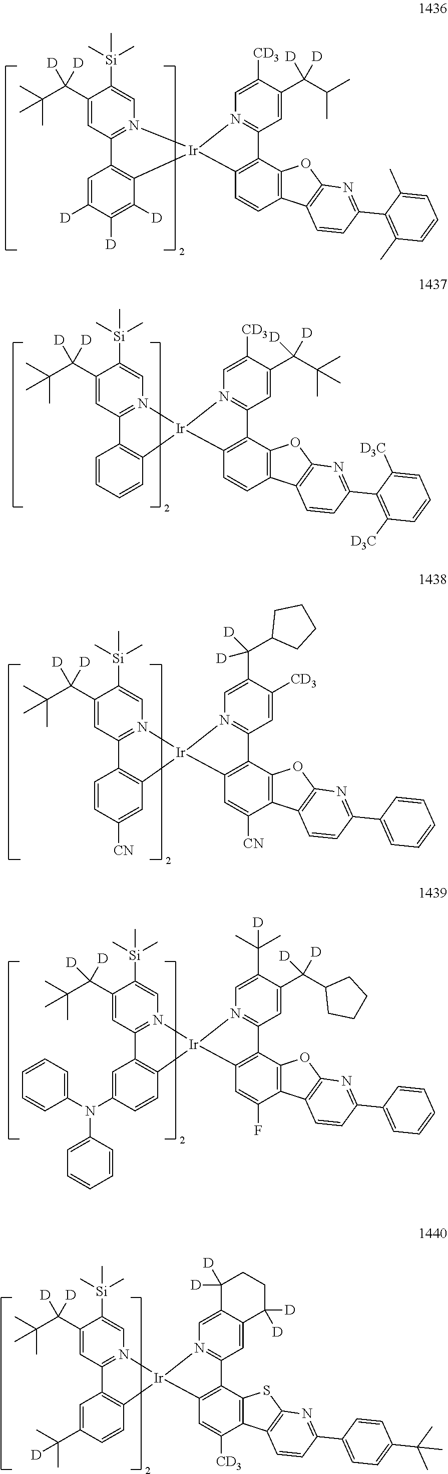

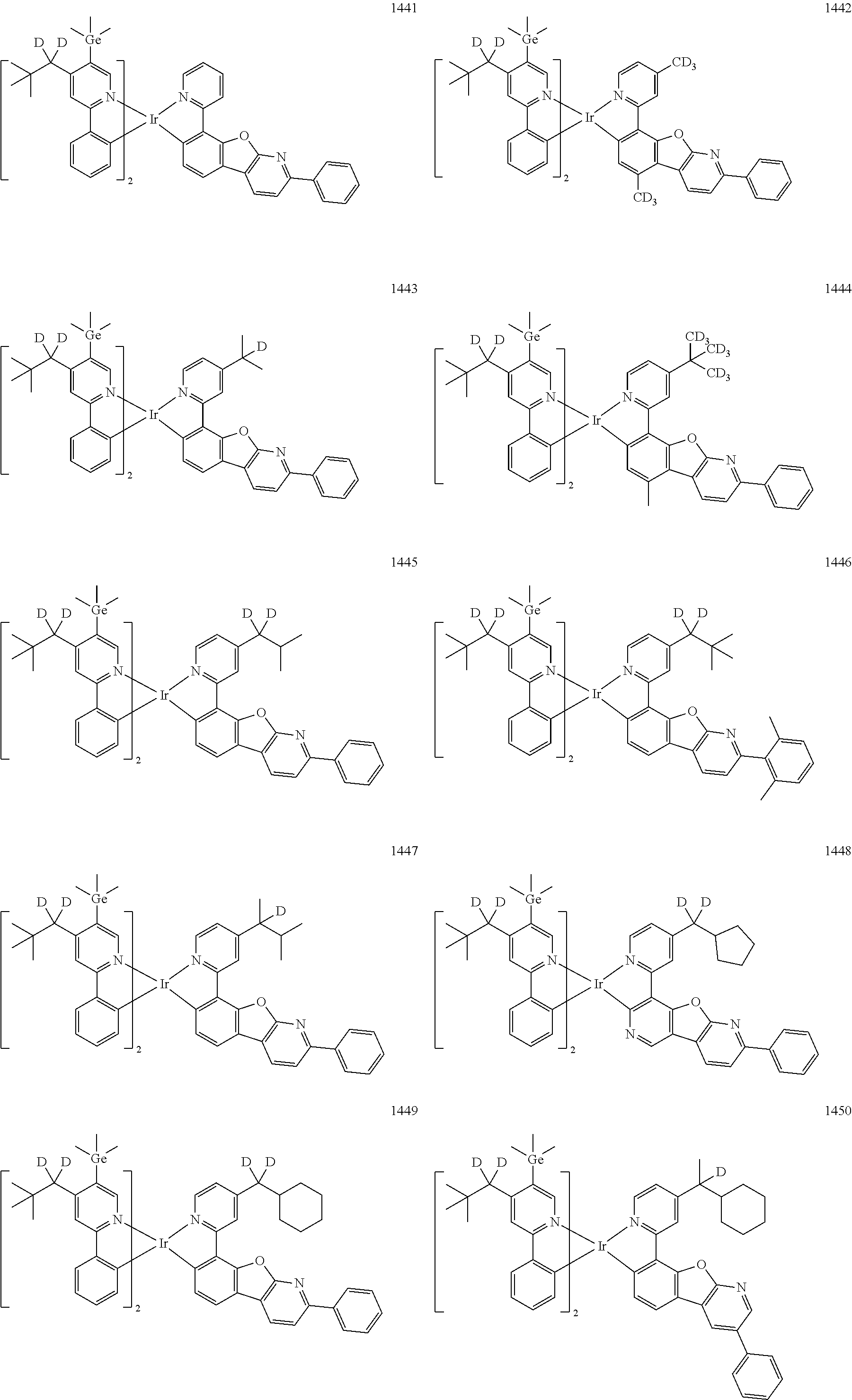

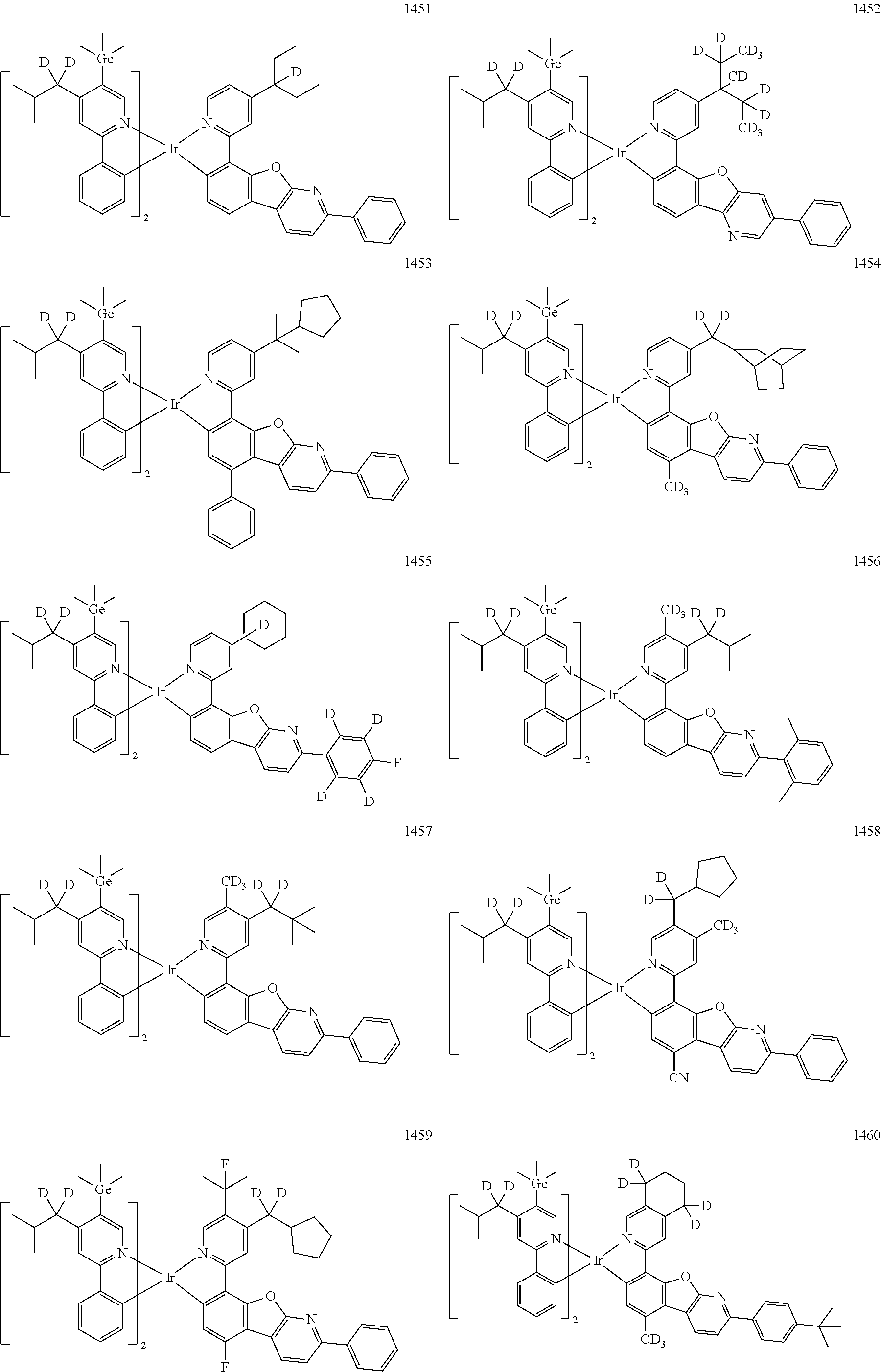

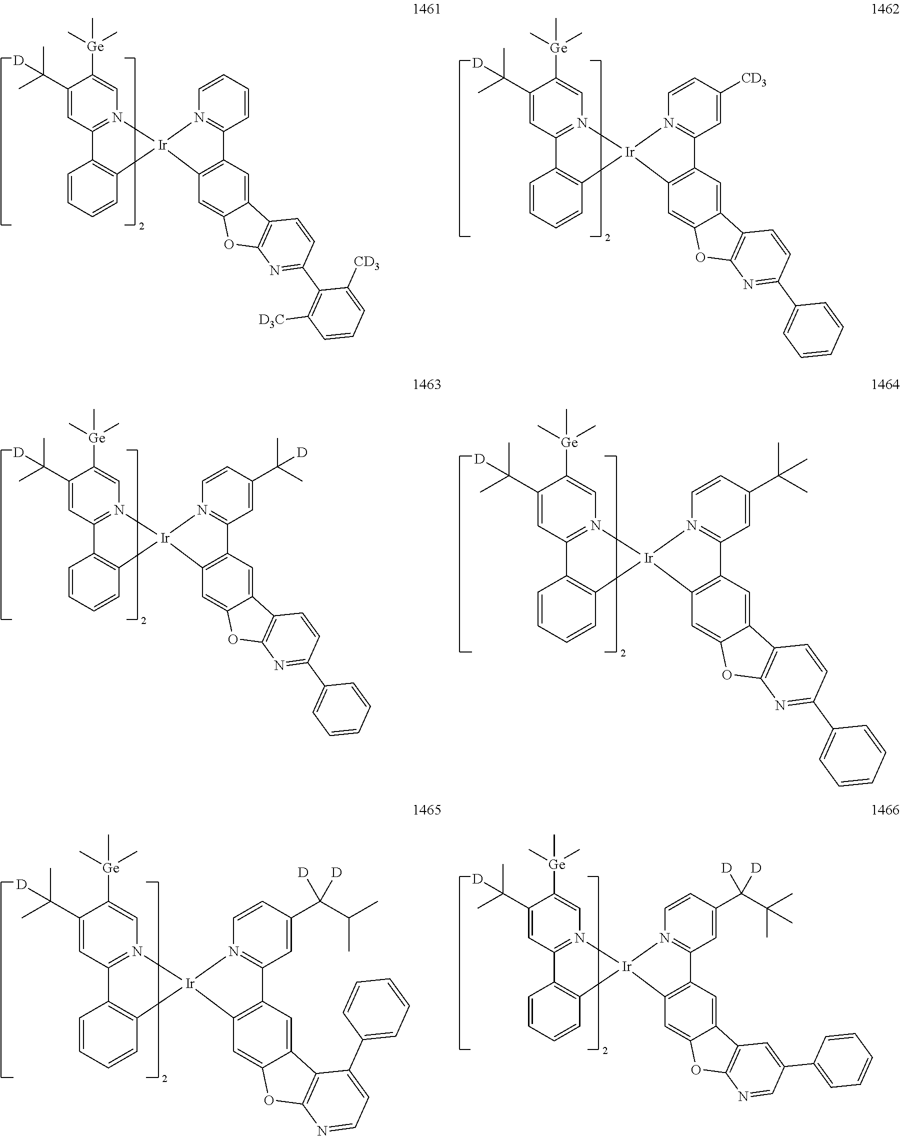

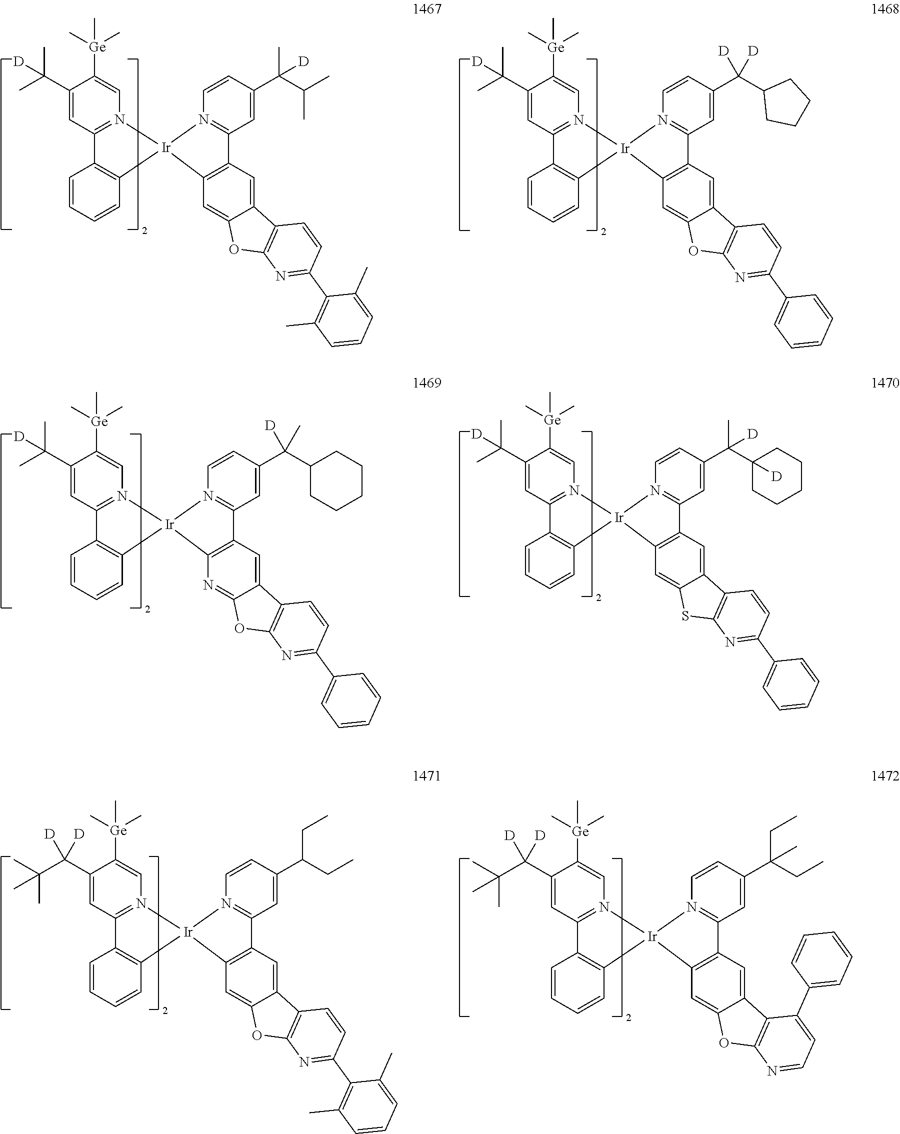

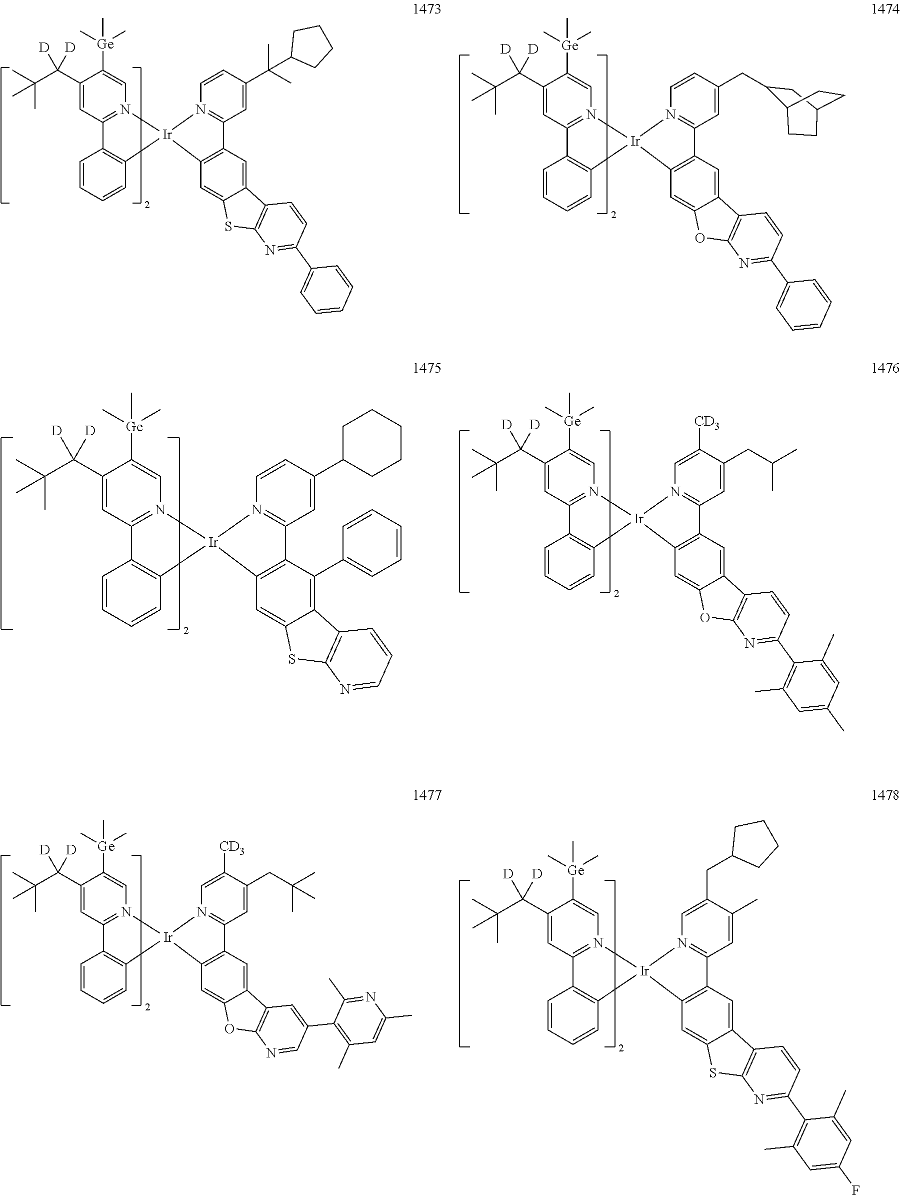

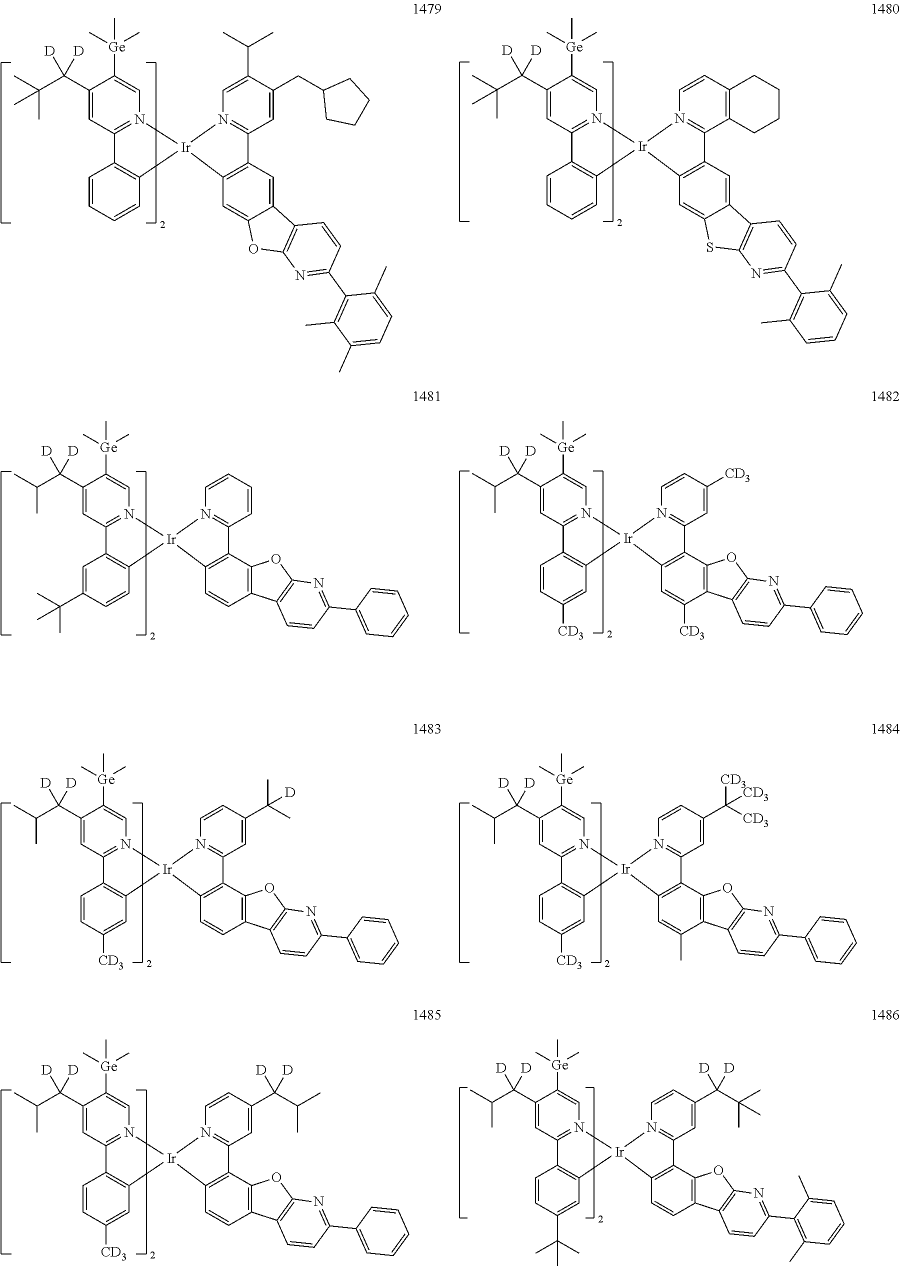

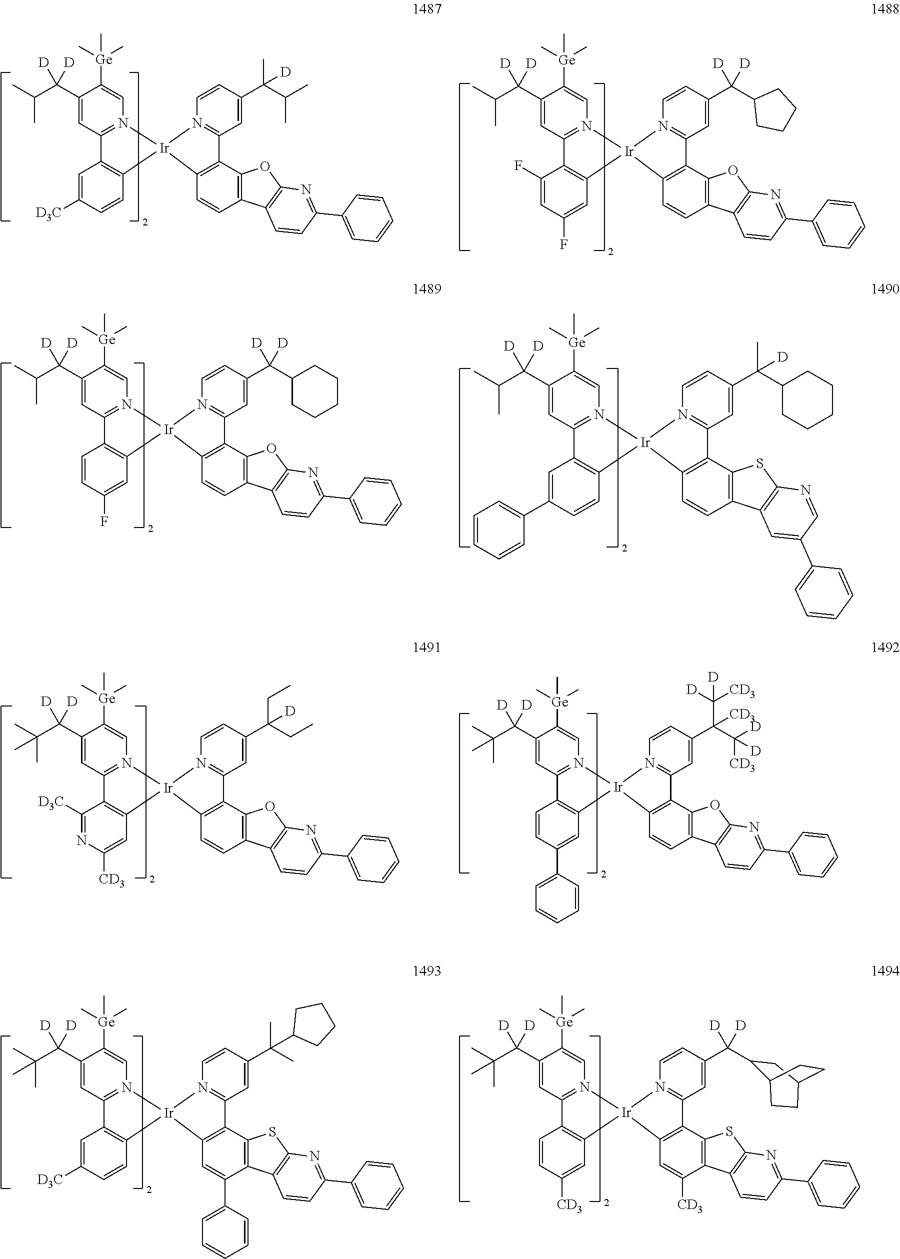

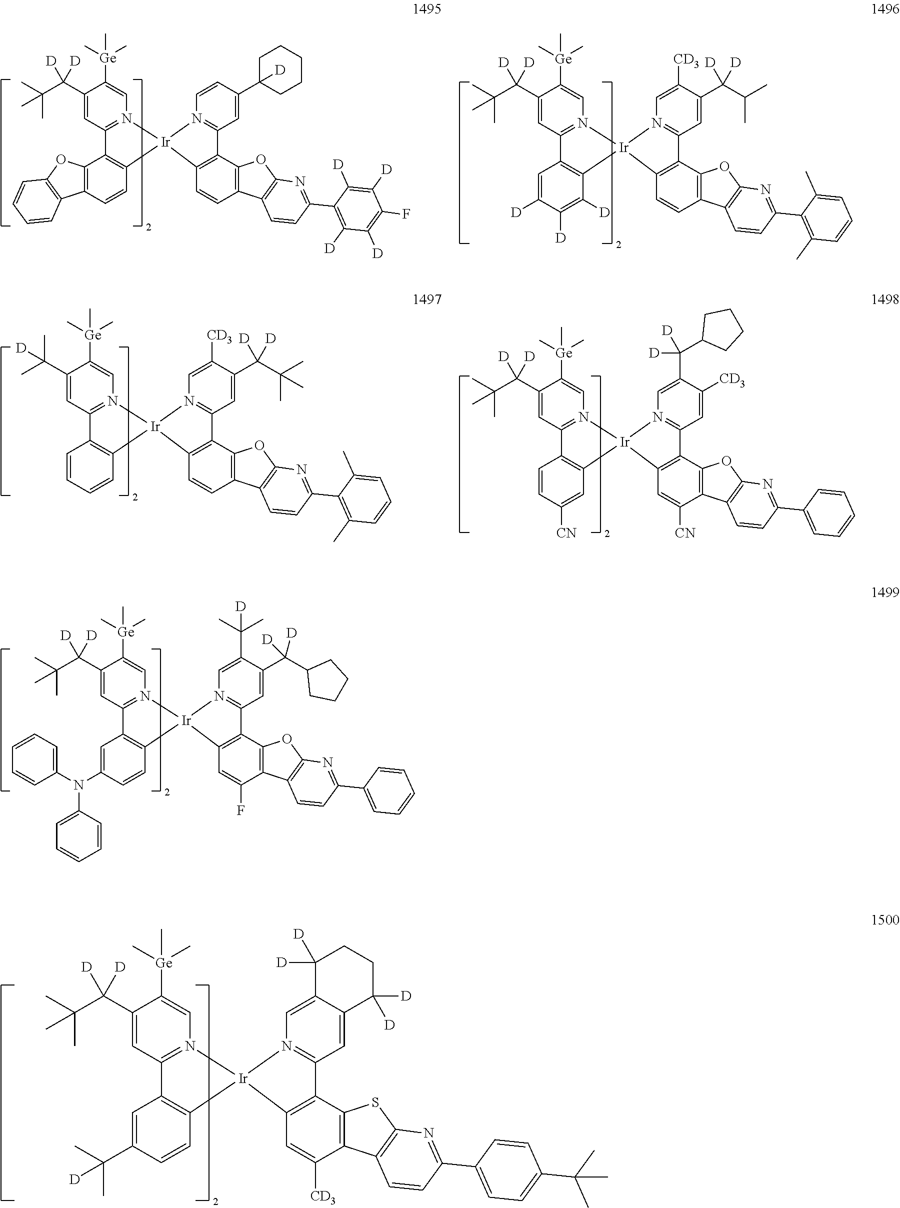

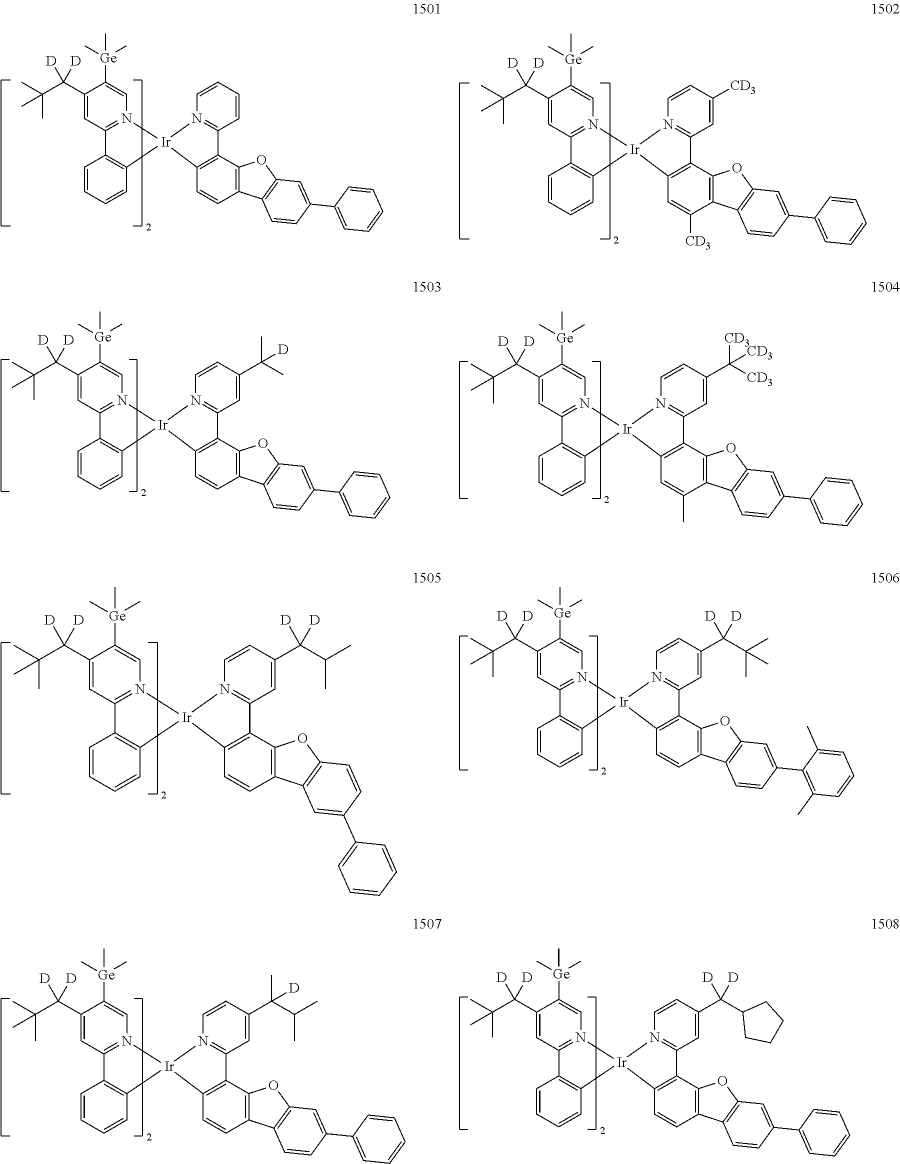

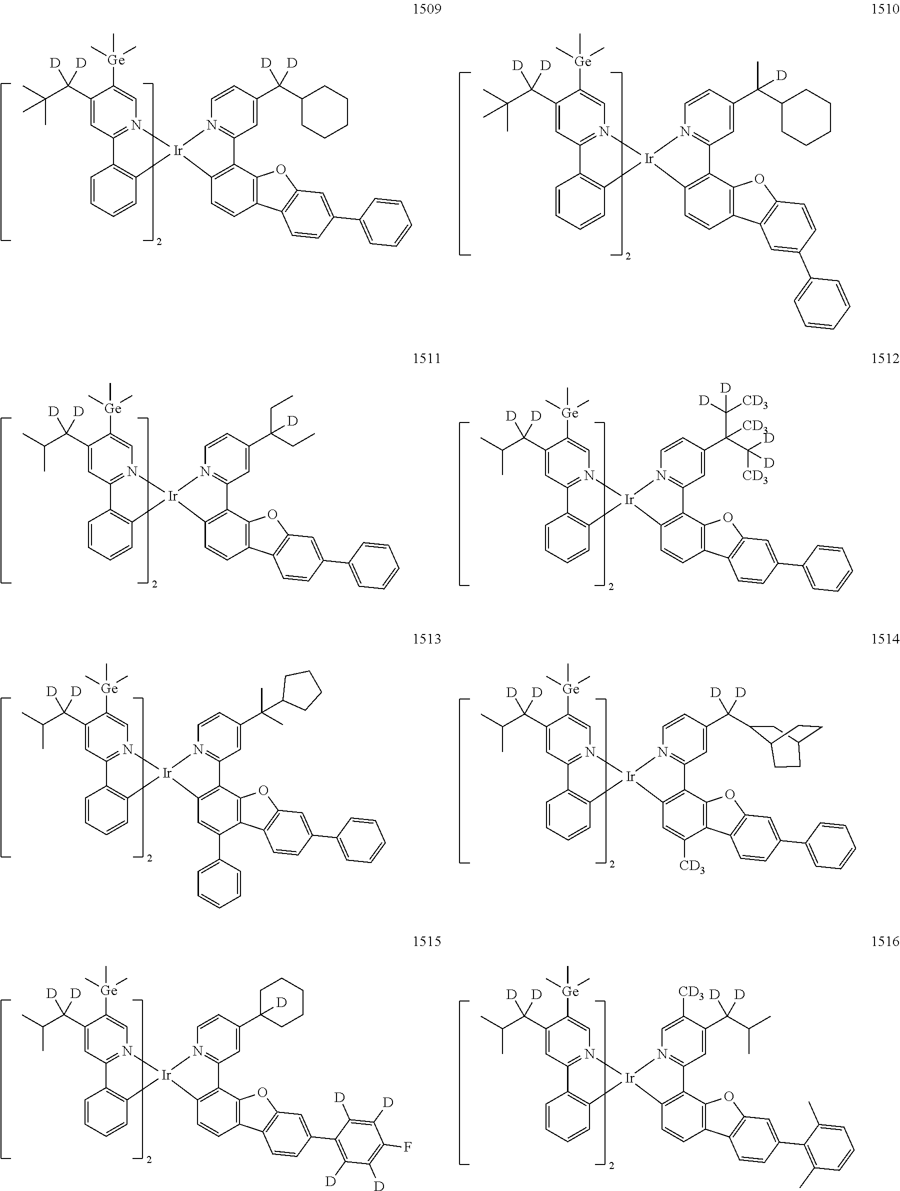

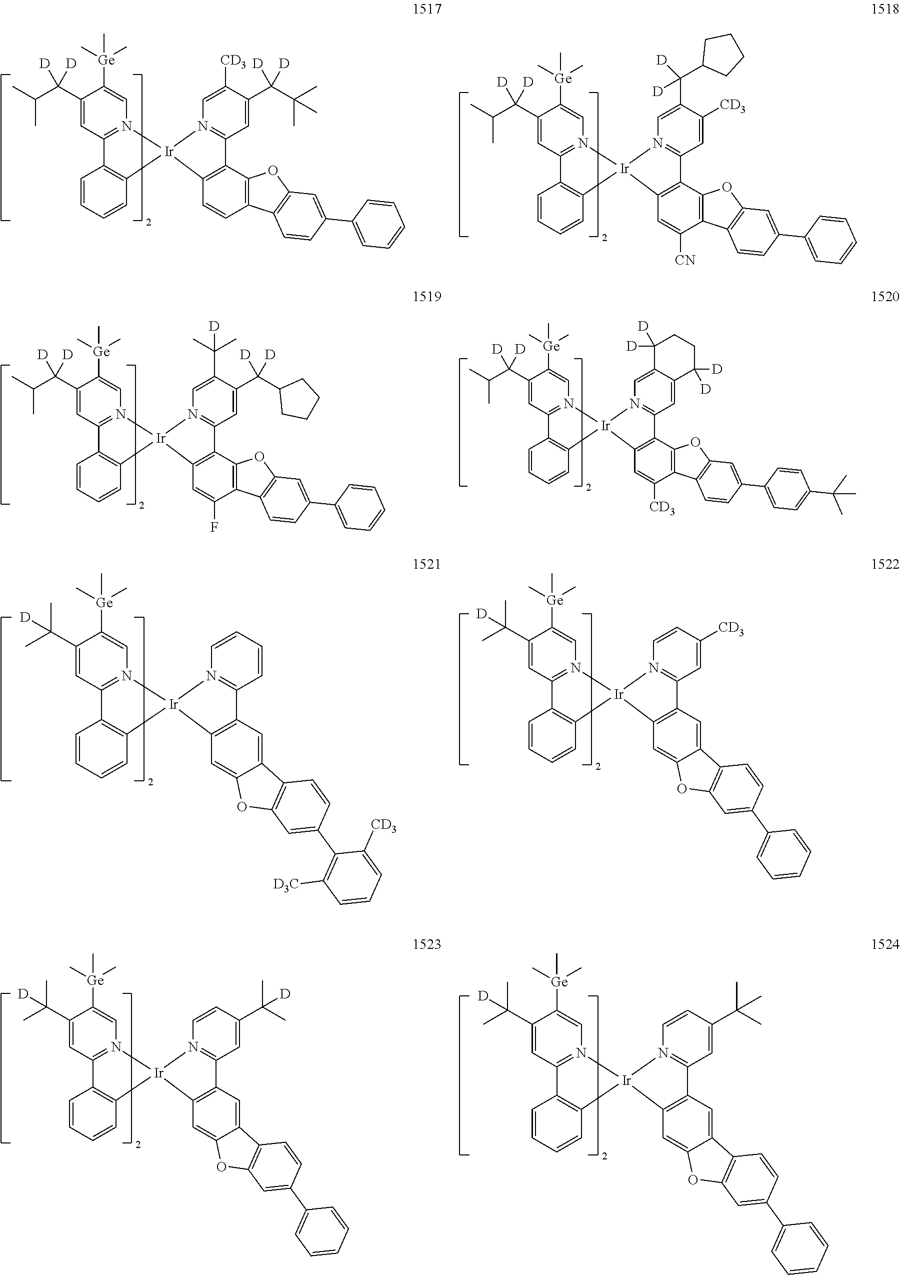

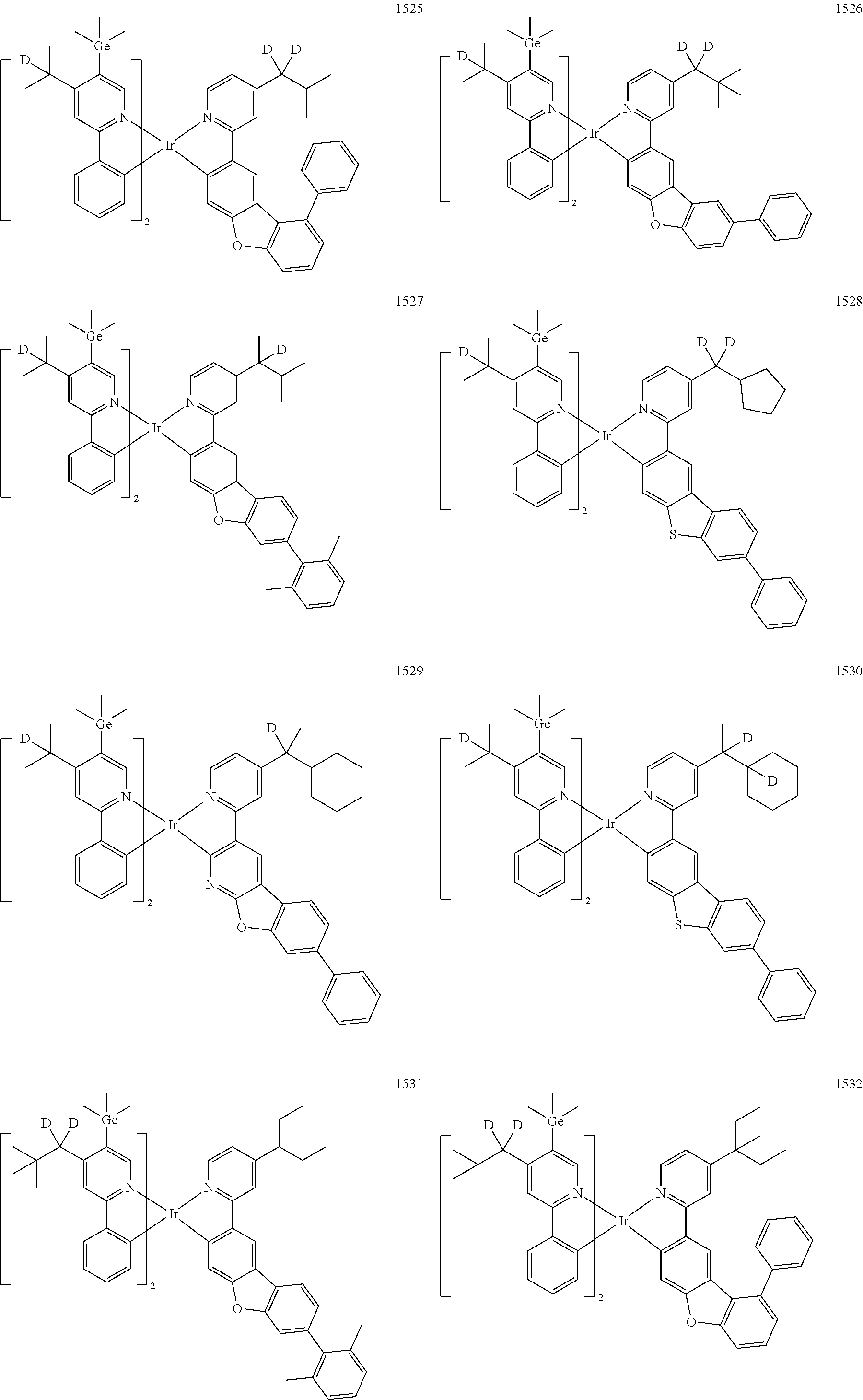

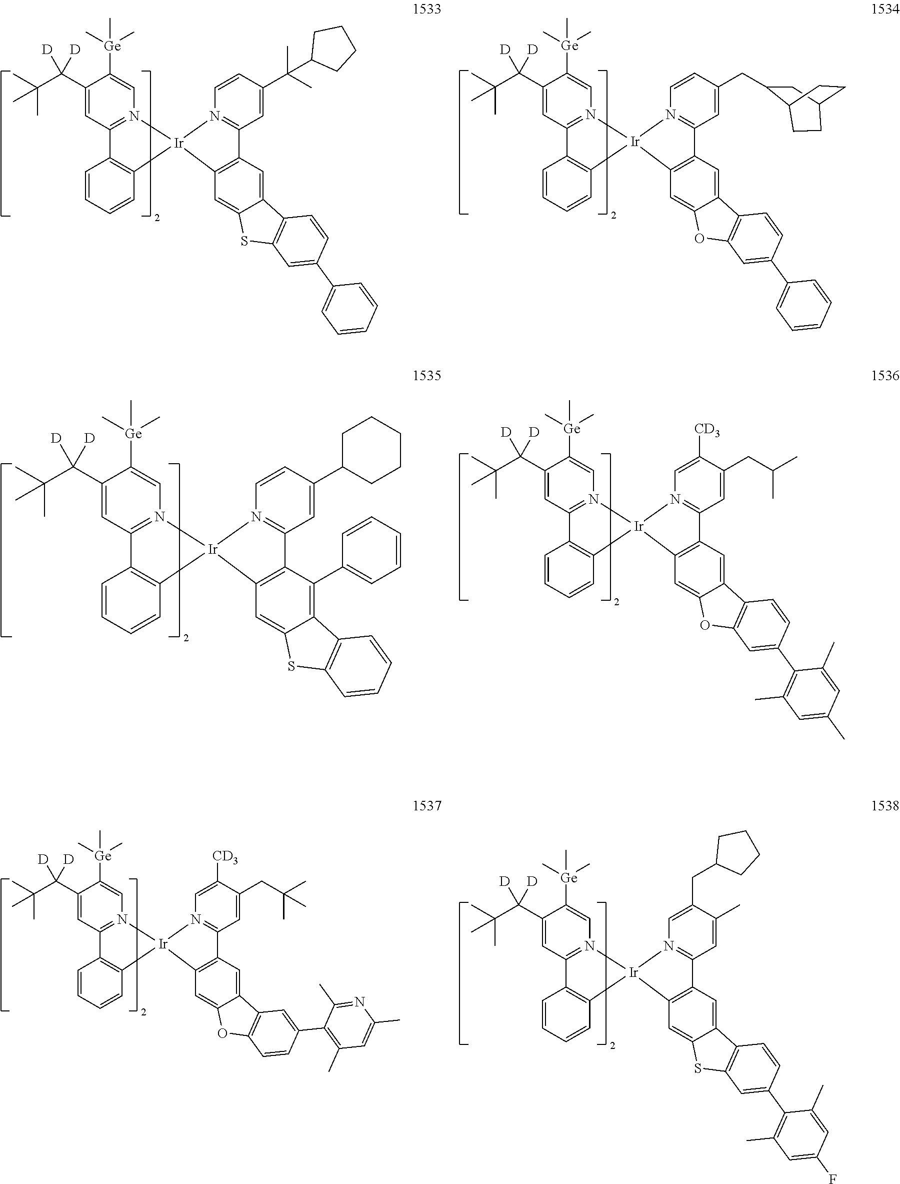

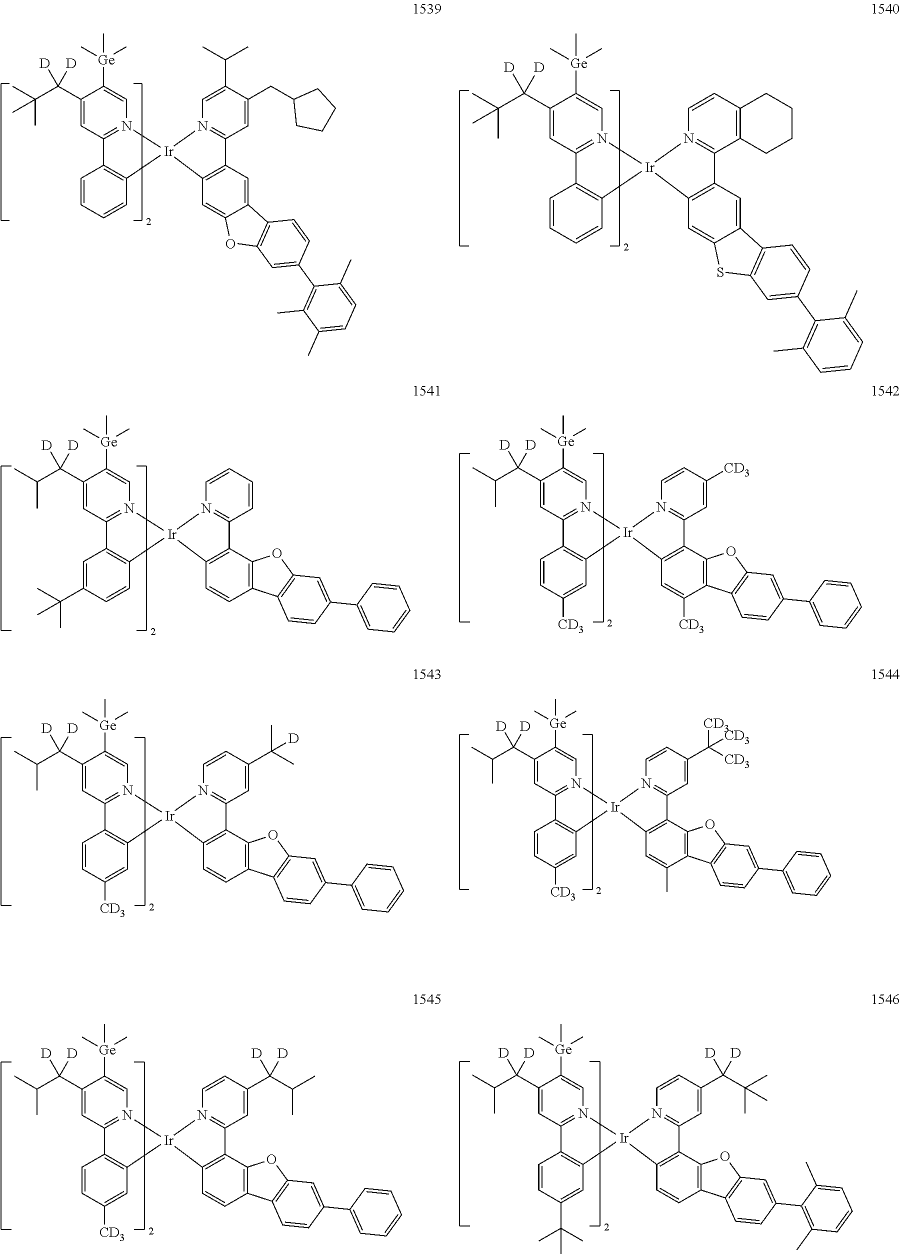

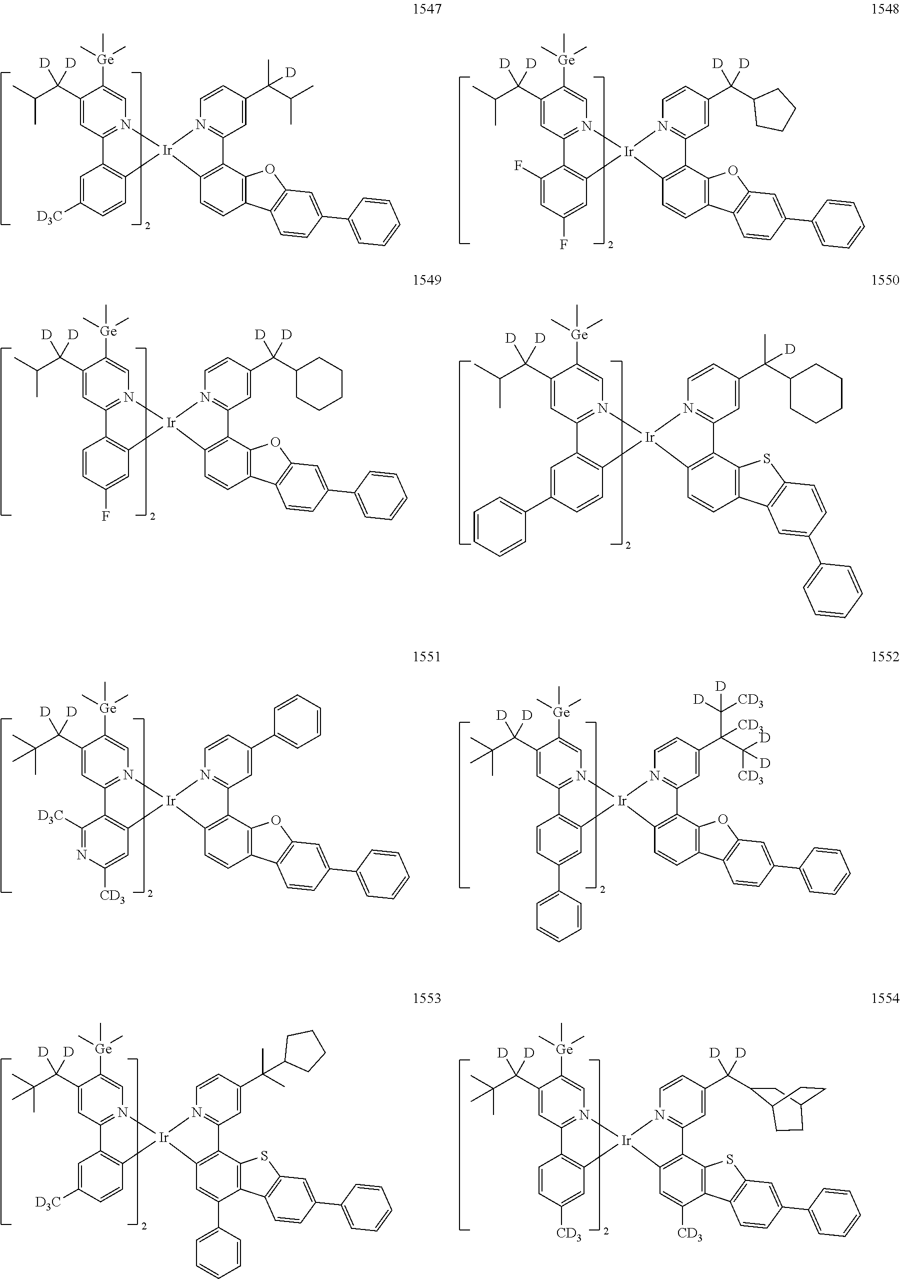

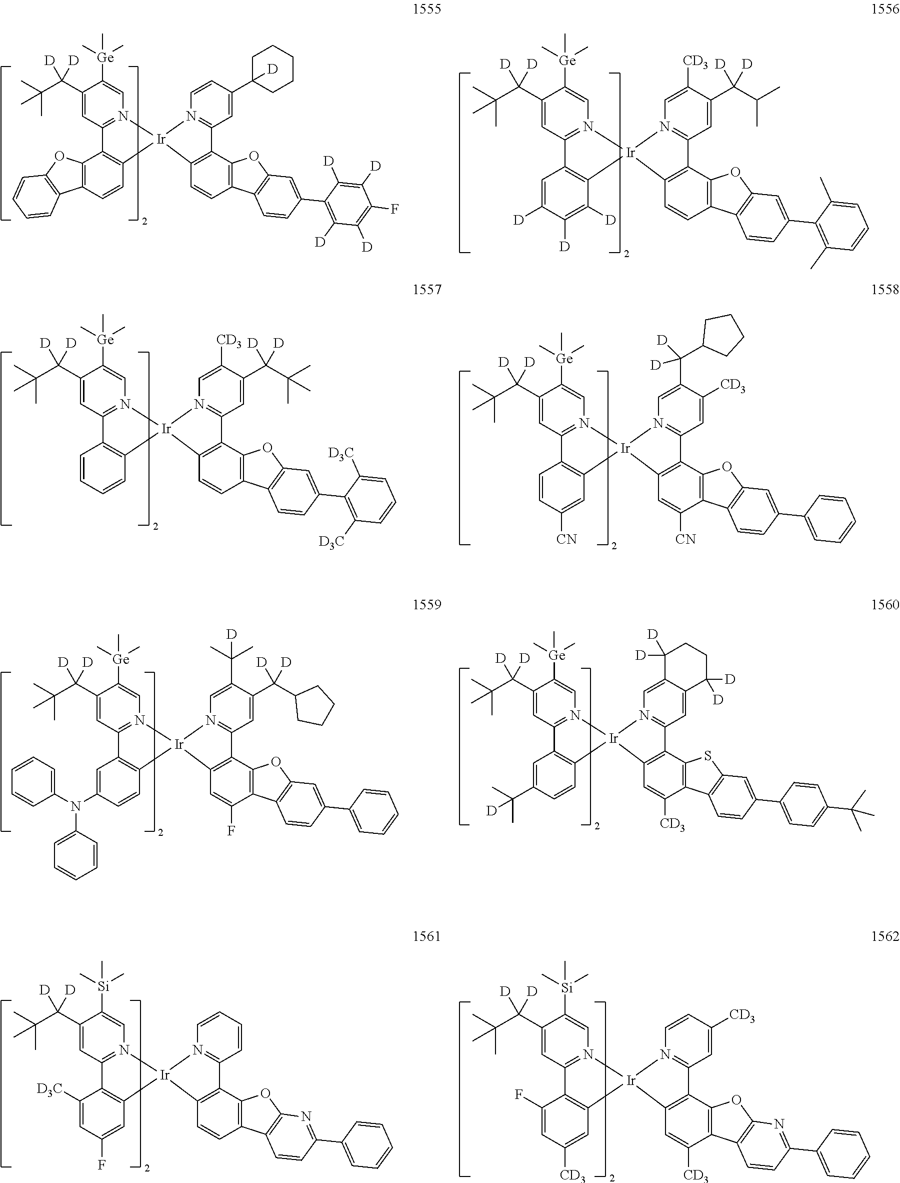

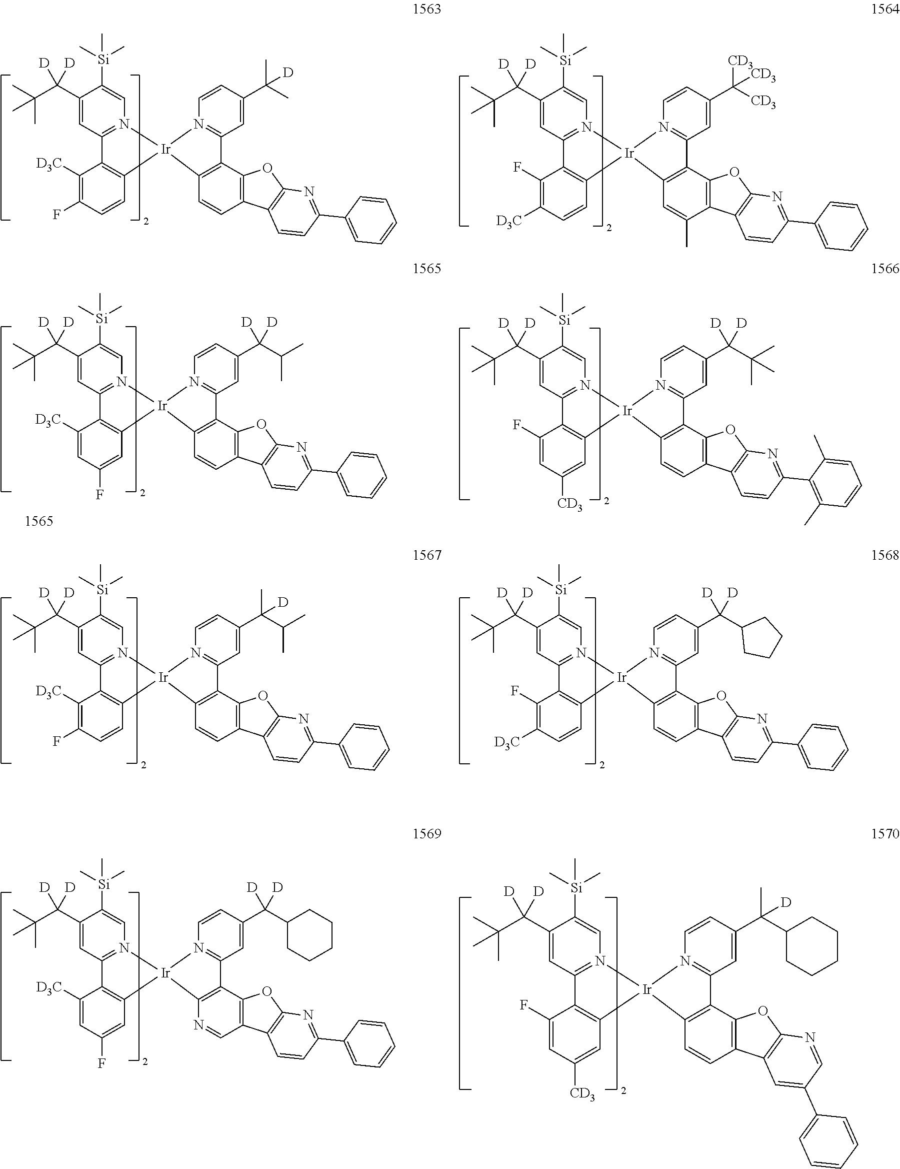

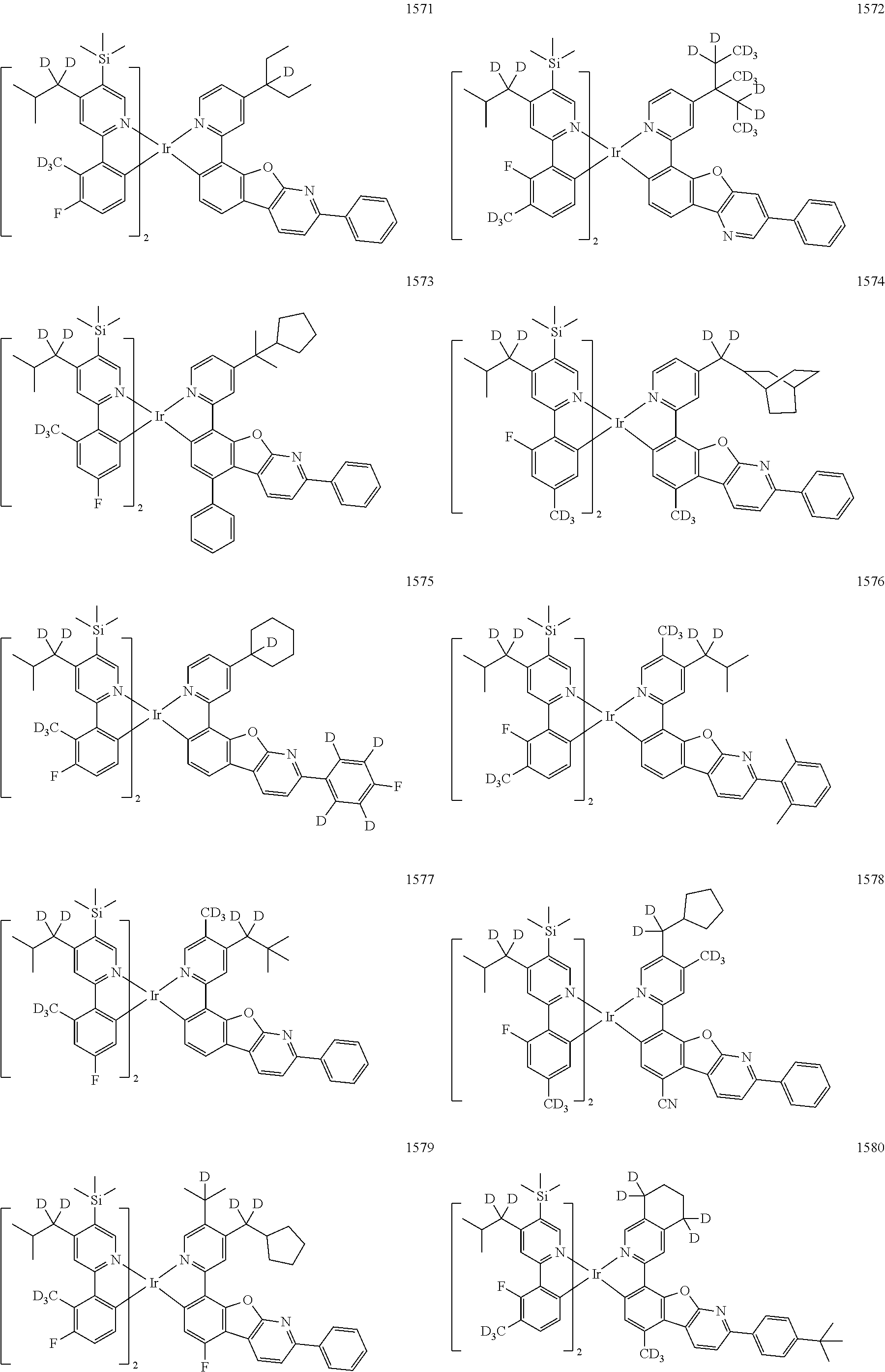

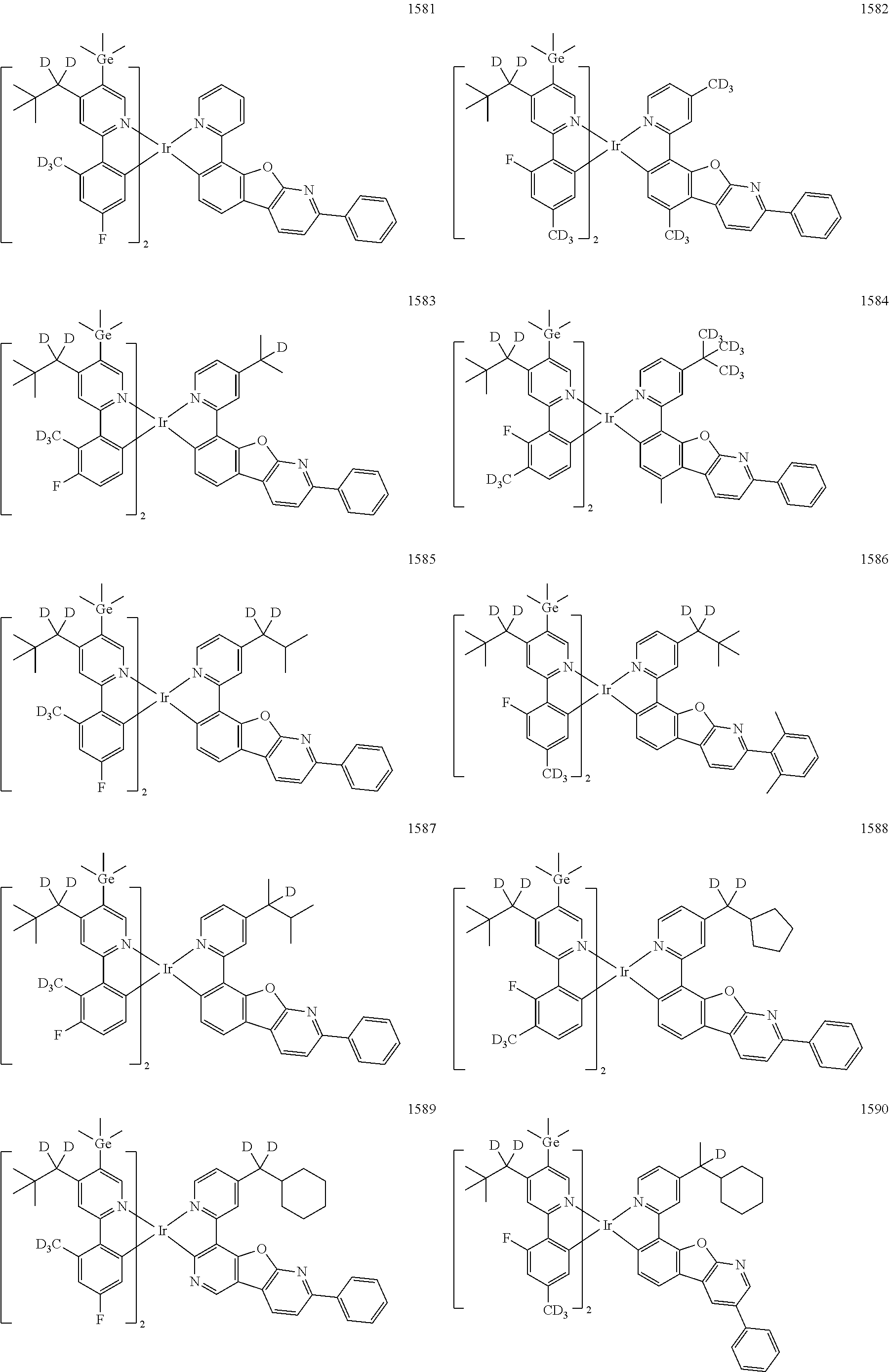

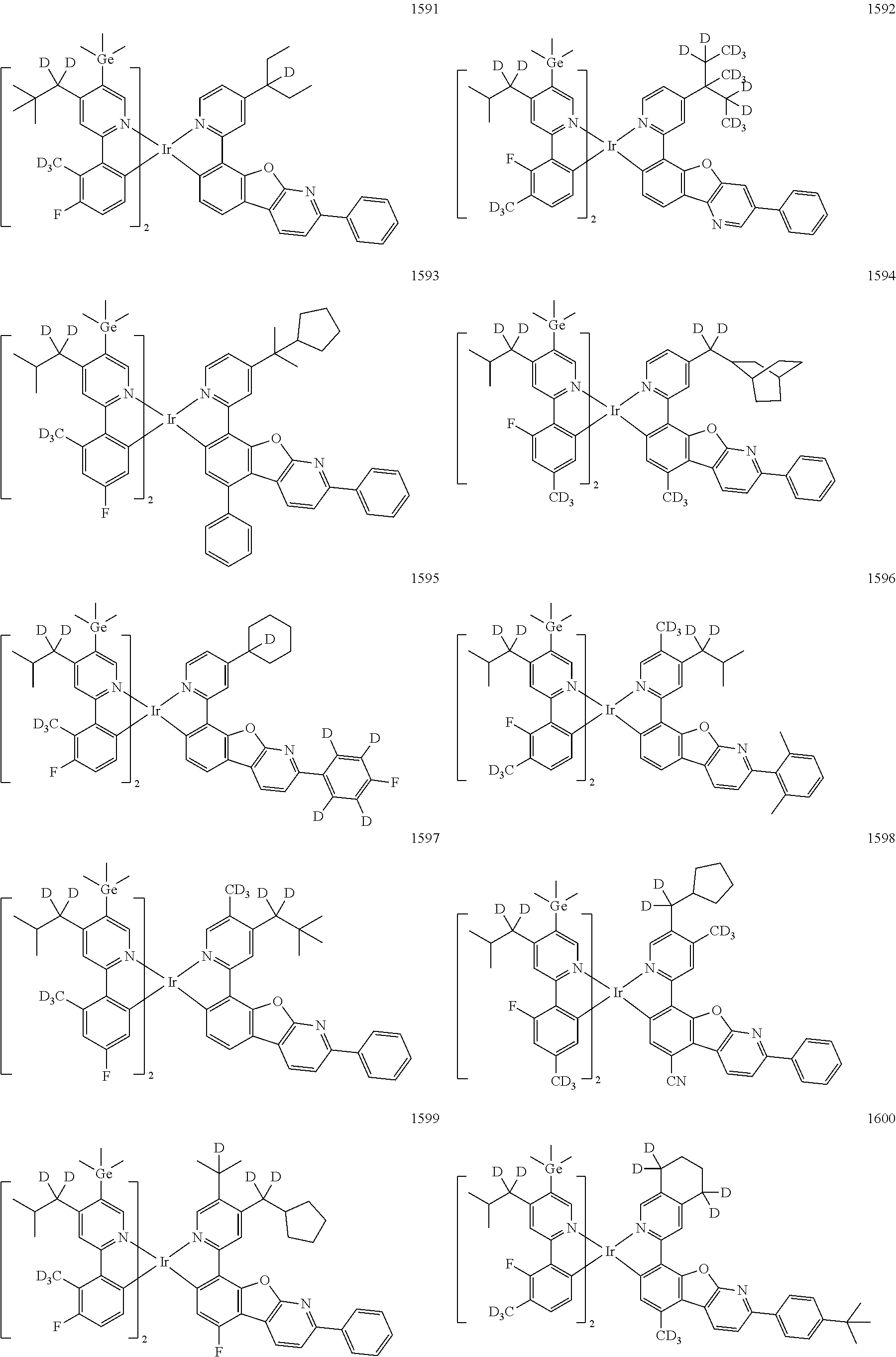

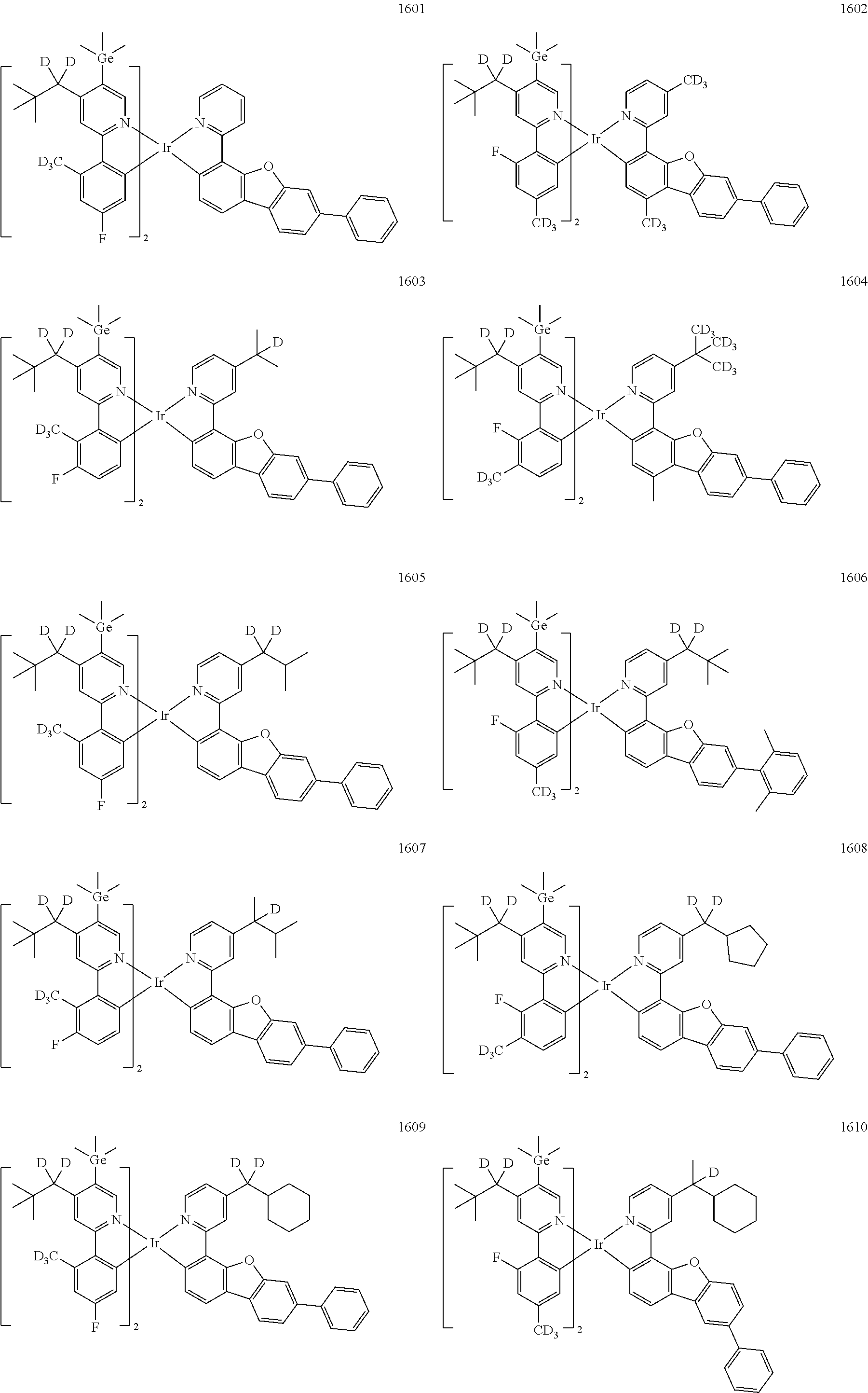

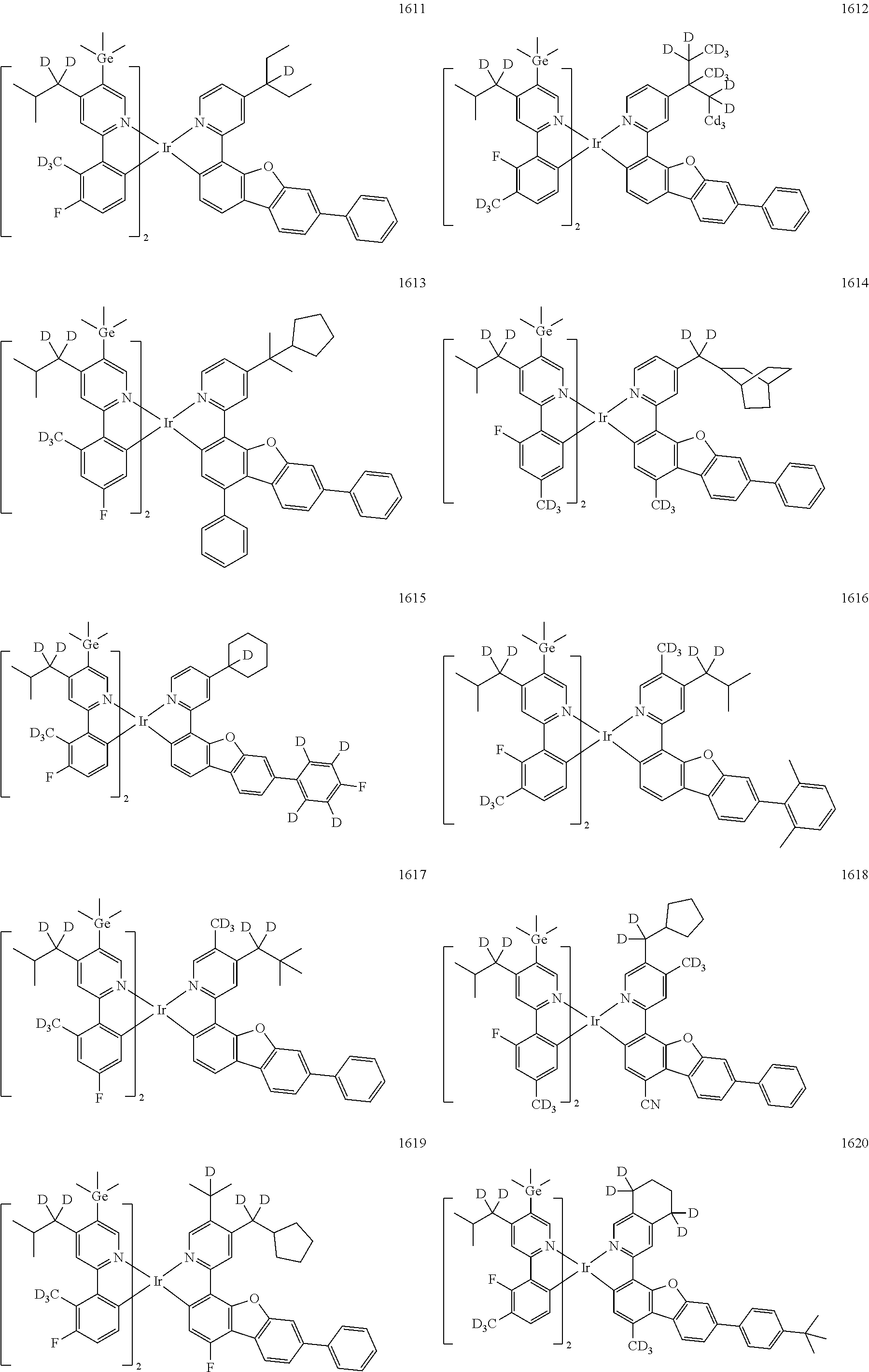

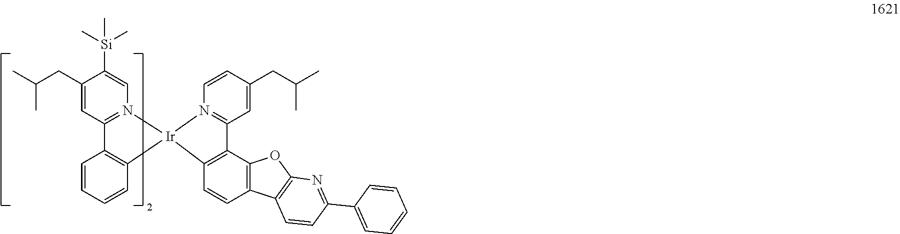

wherein, in Compounds 1 to 1621 of Group G1-1, OMe indicates a methoxy group.

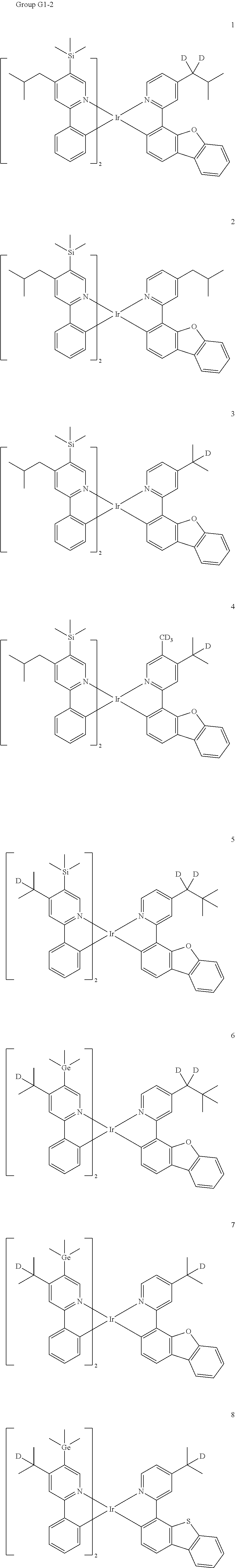

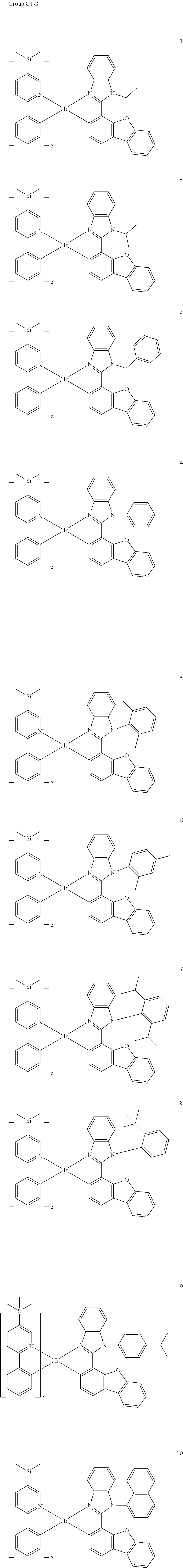

[chemical structure]

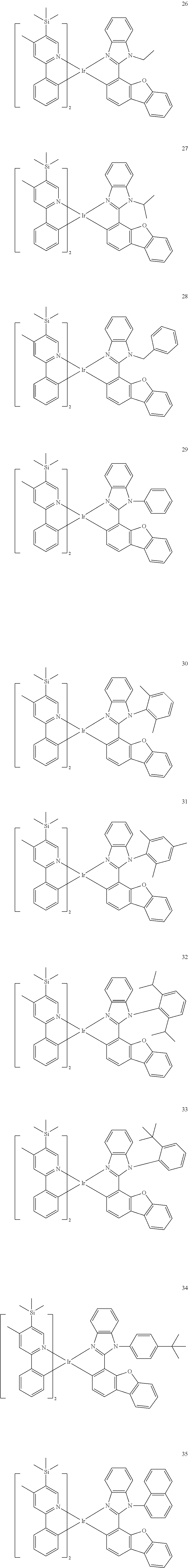

[chemical structure]

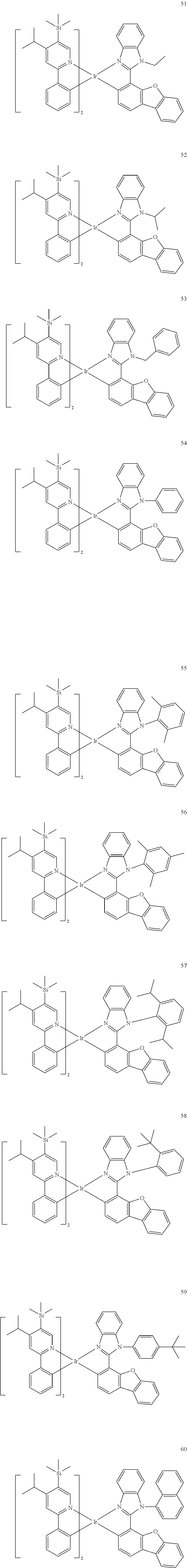

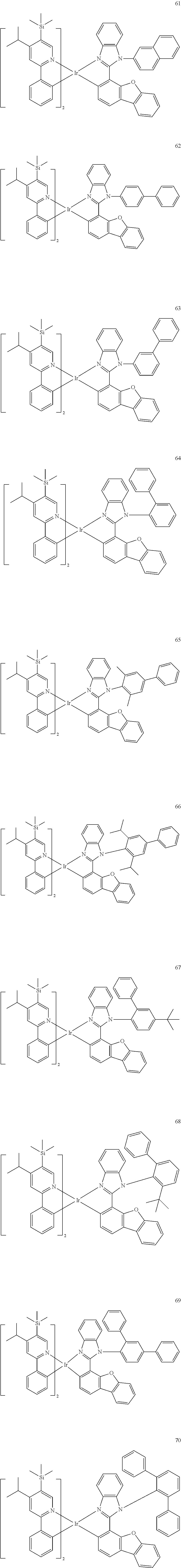

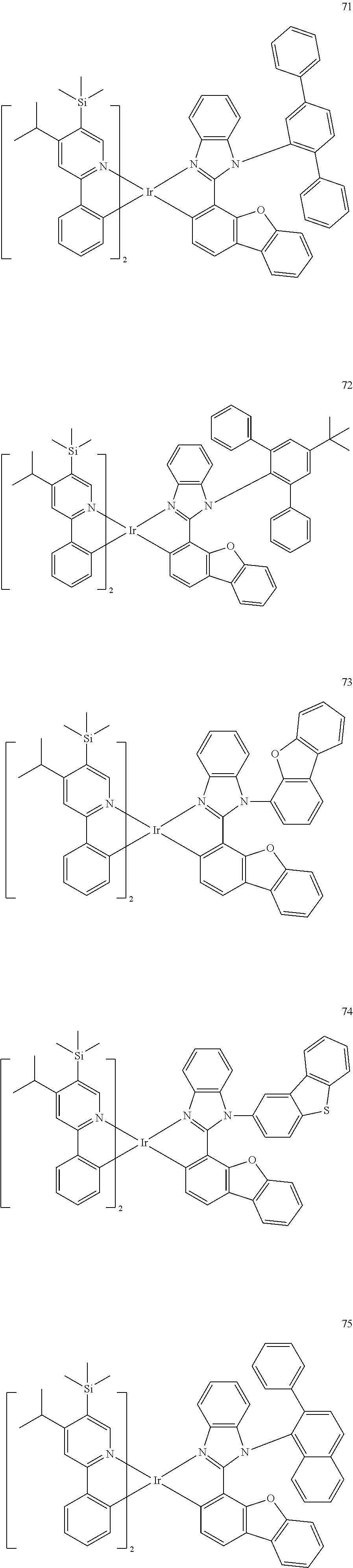

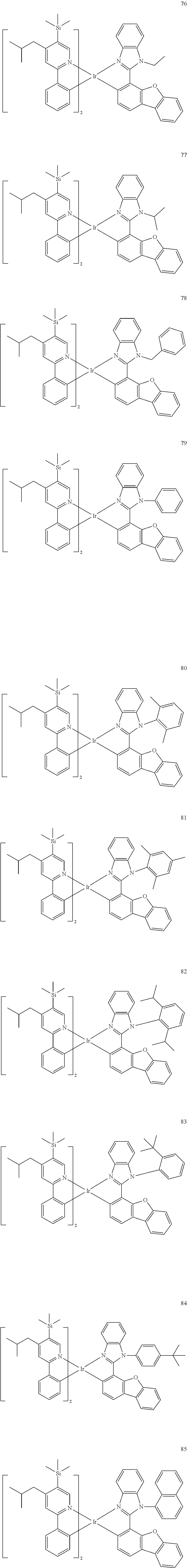

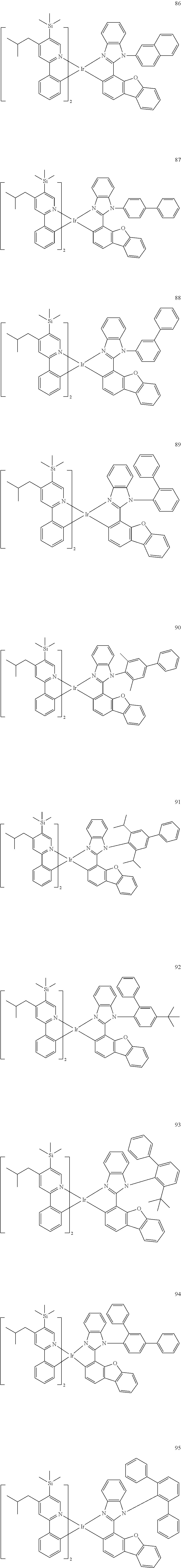

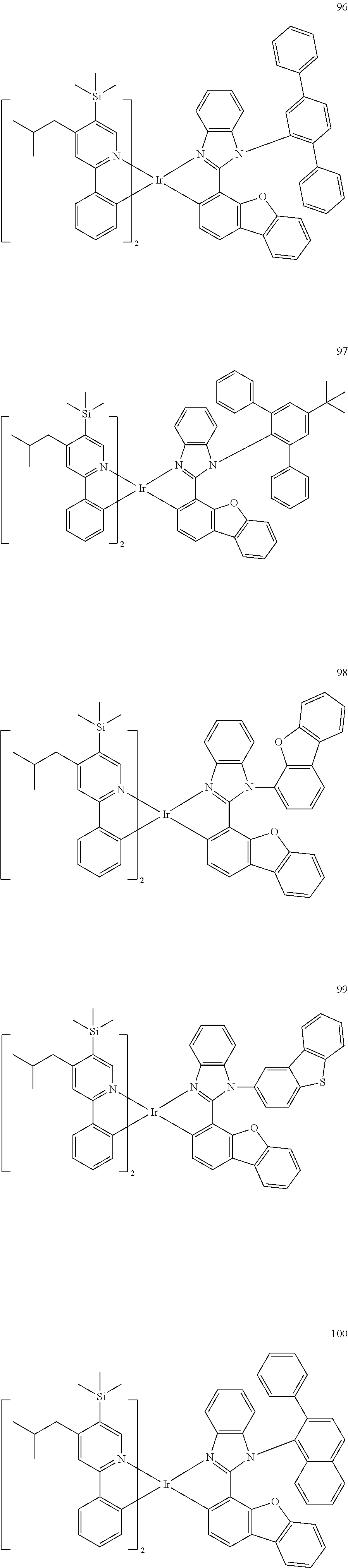

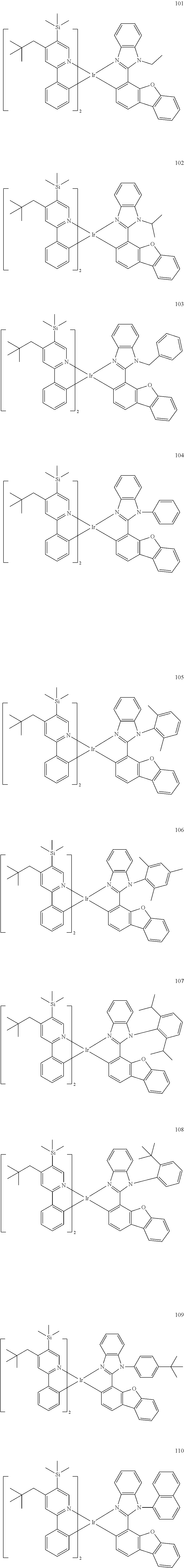

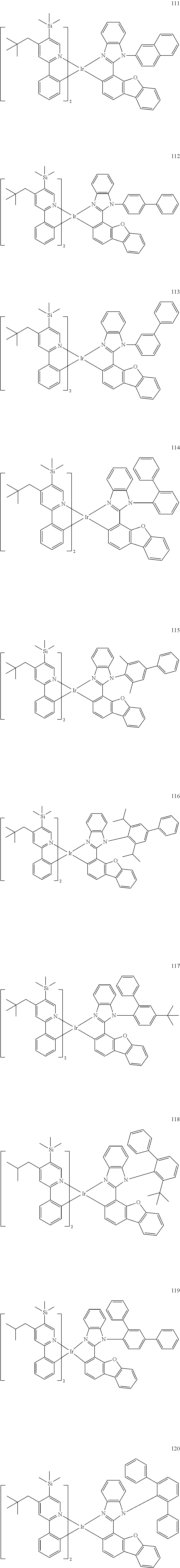

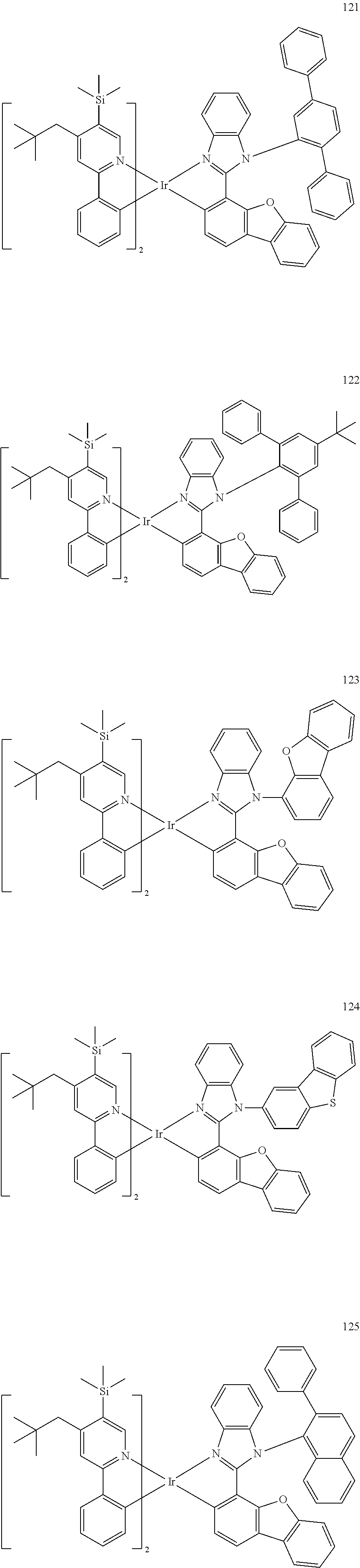

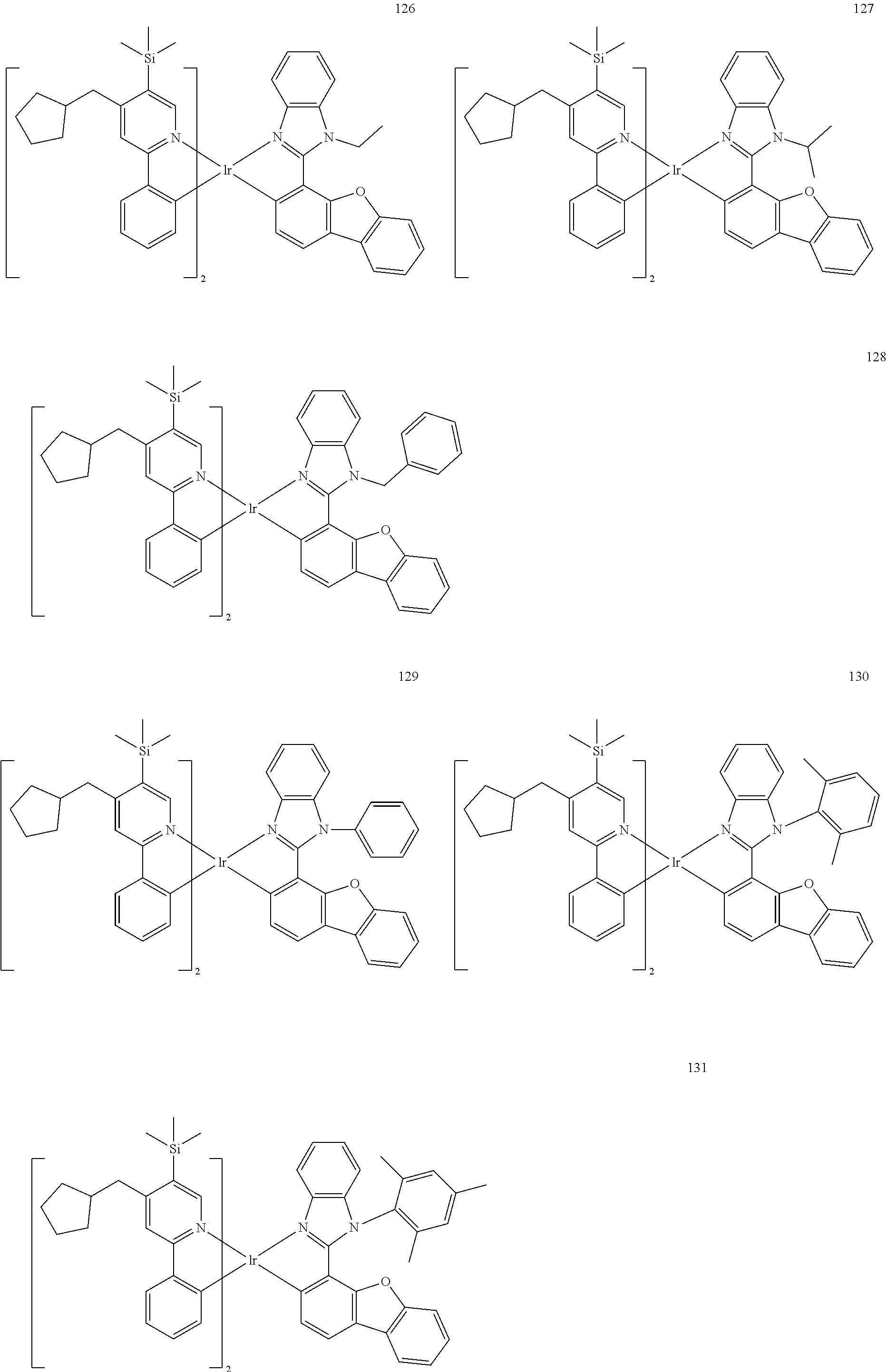

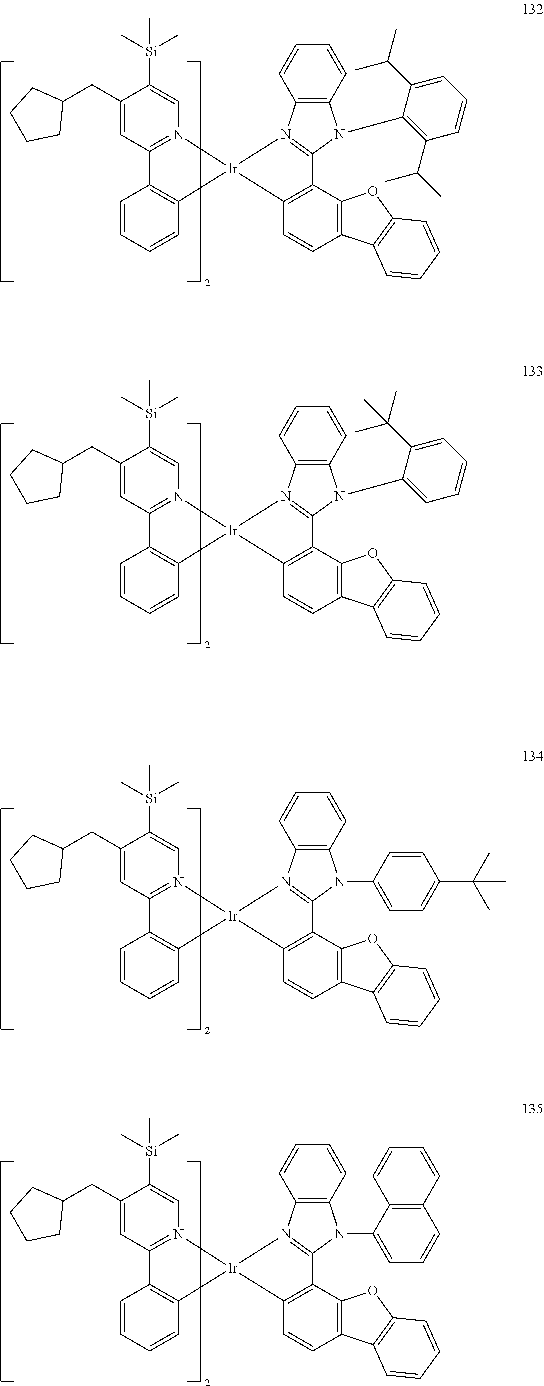

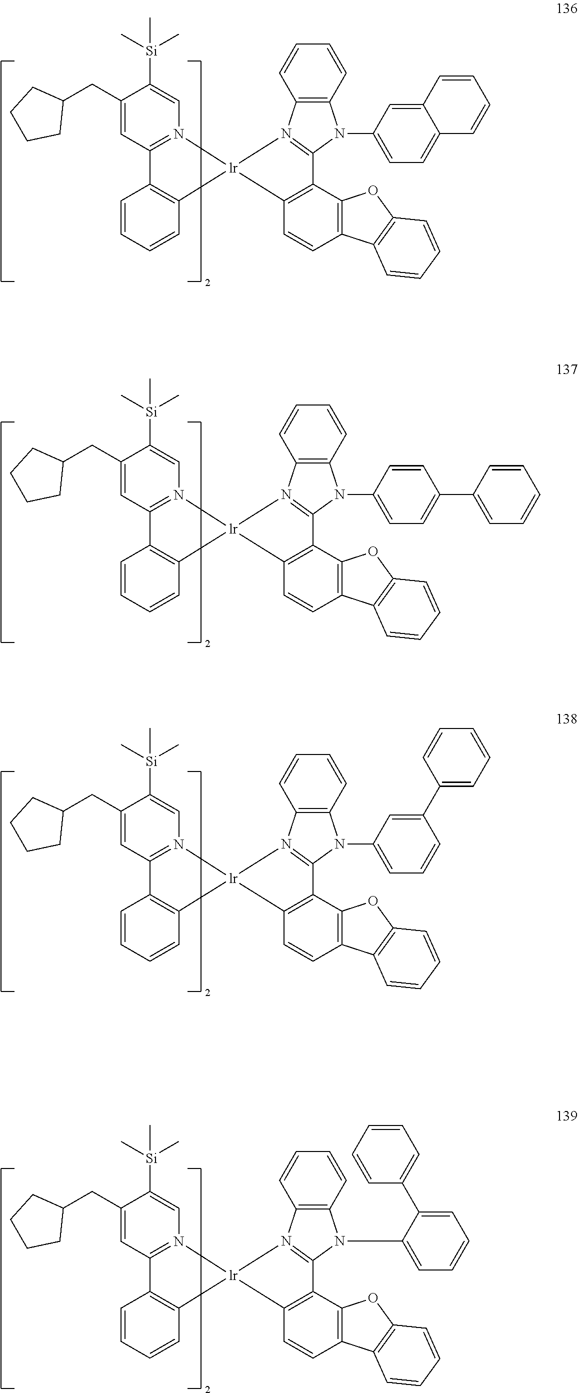

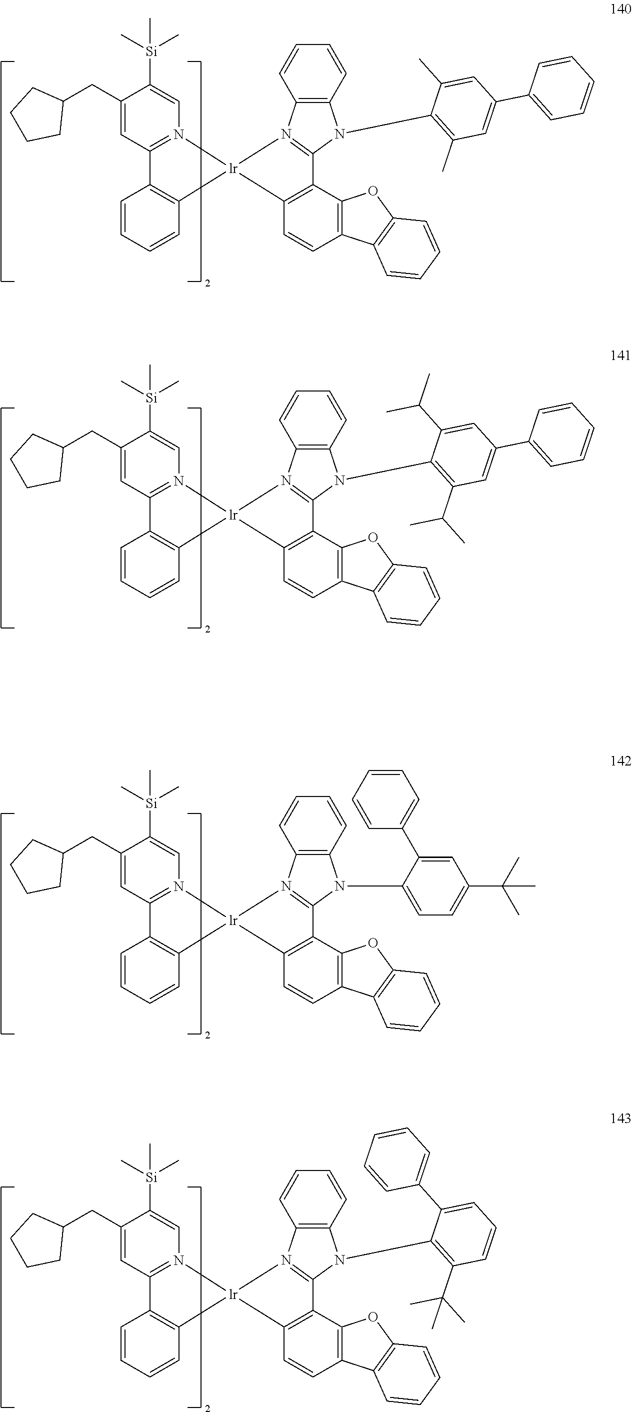

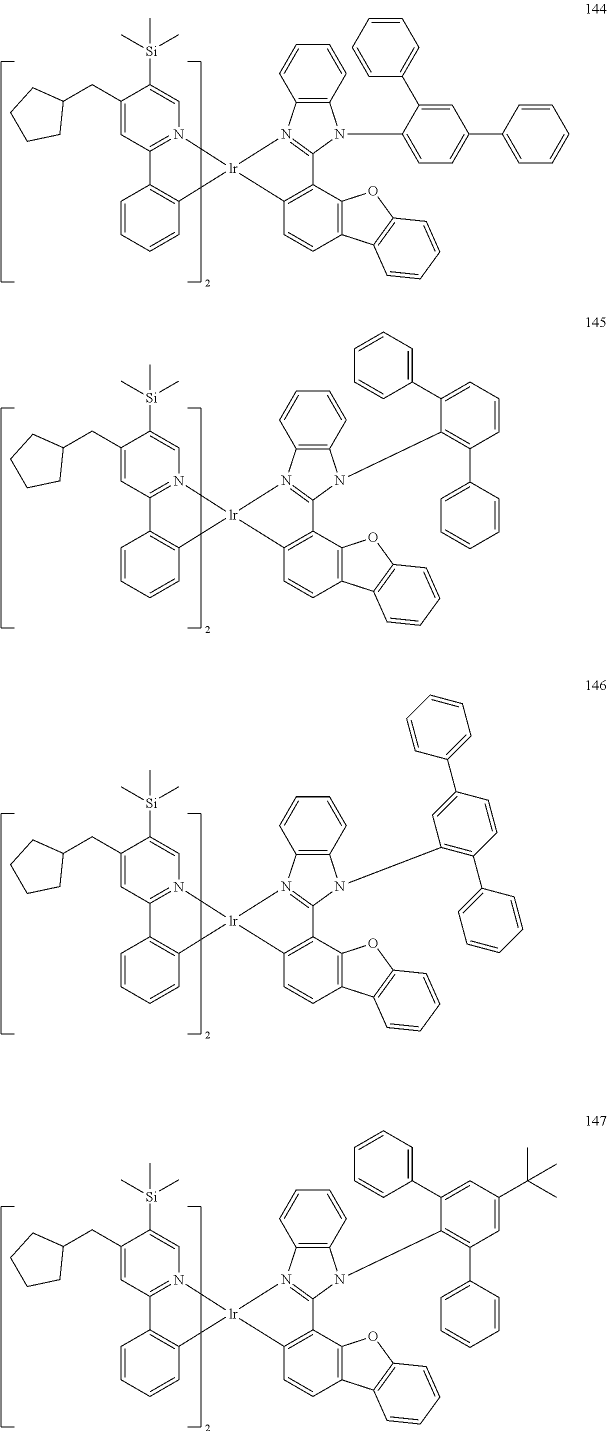

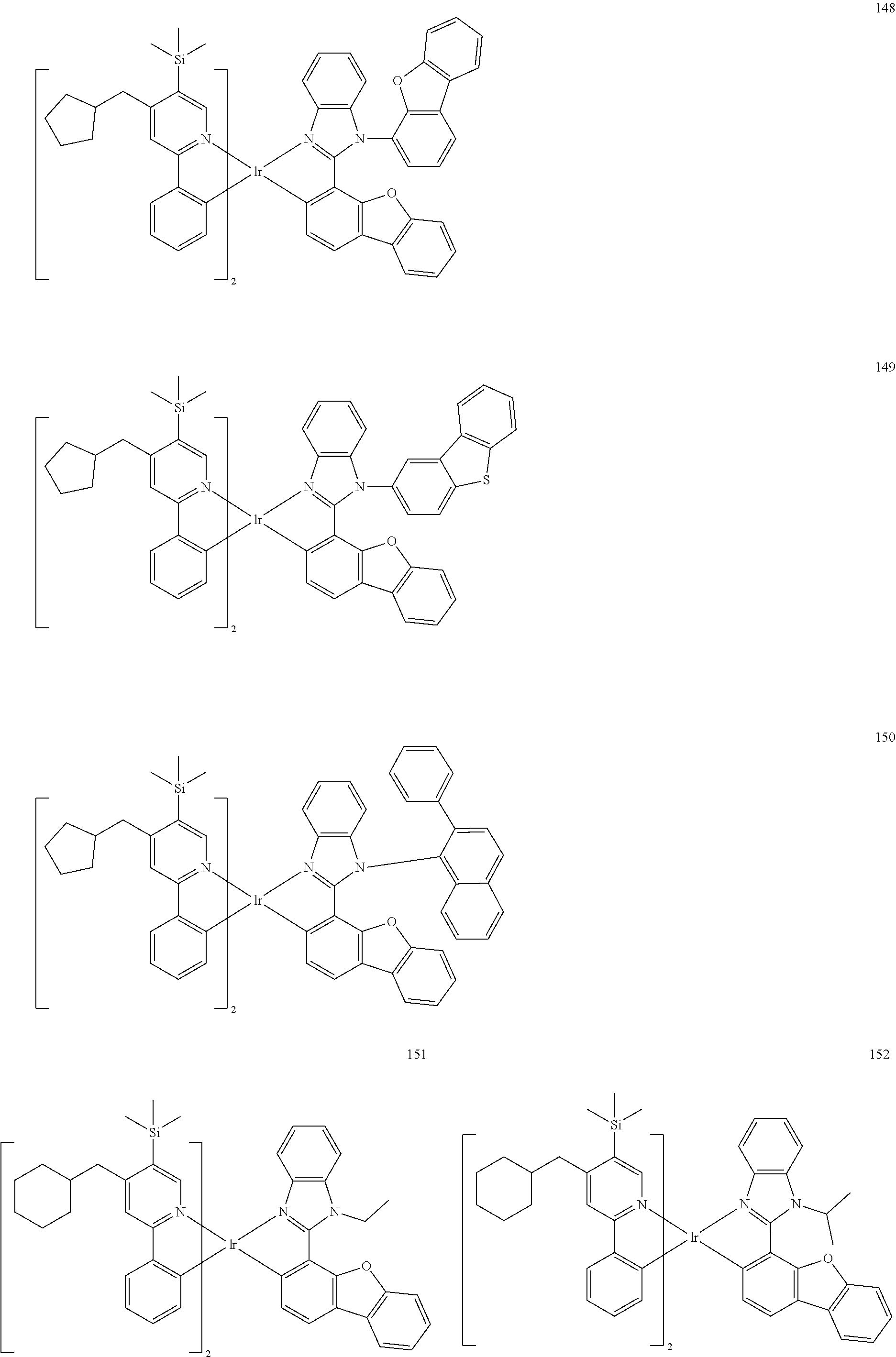

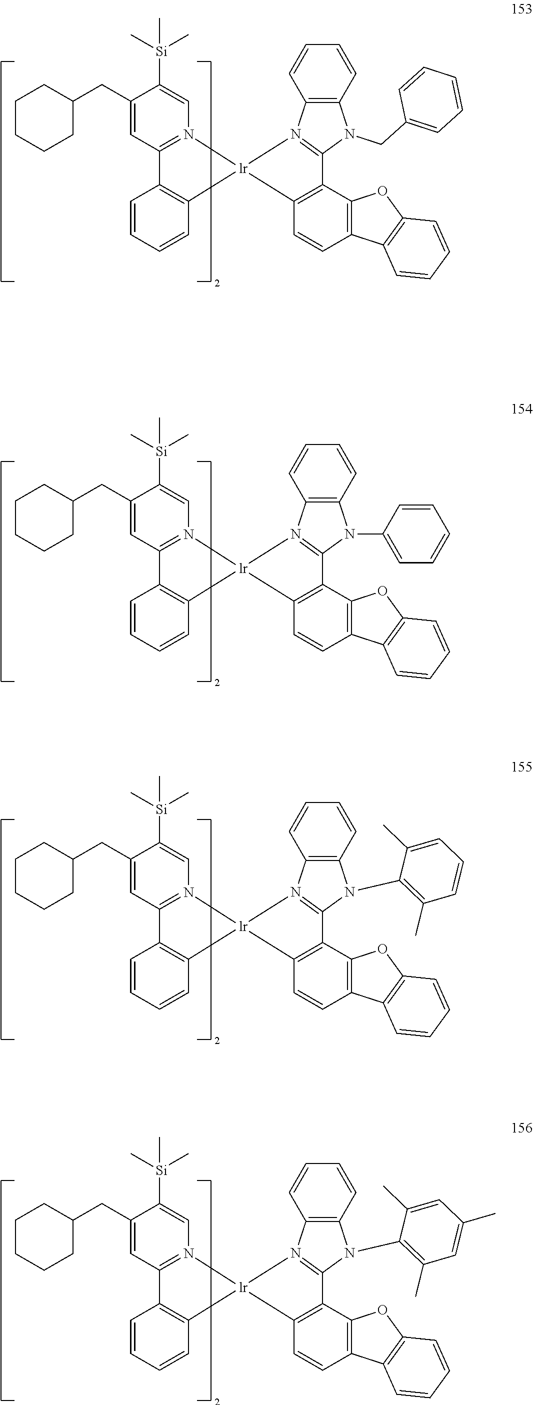

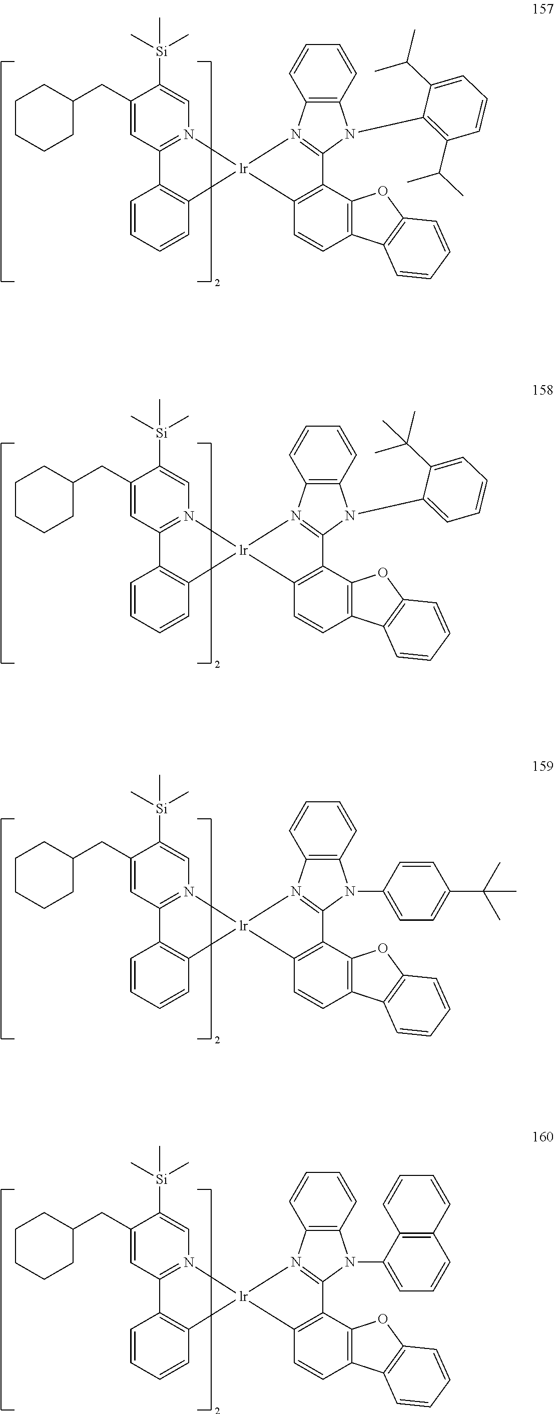

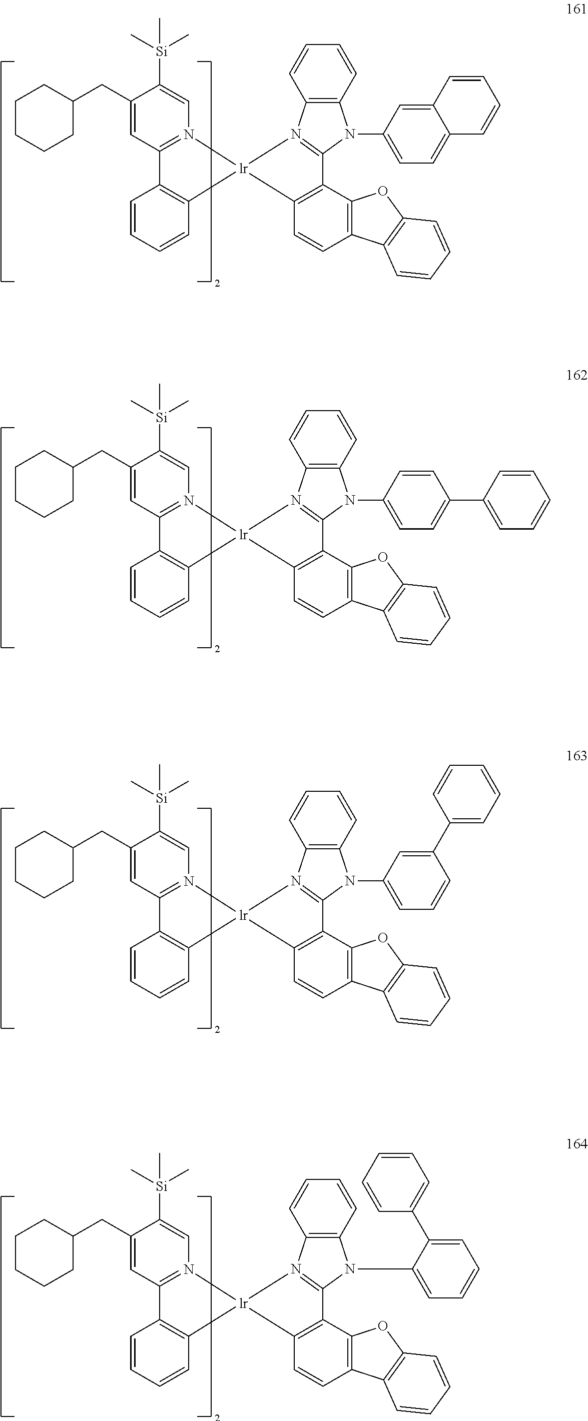

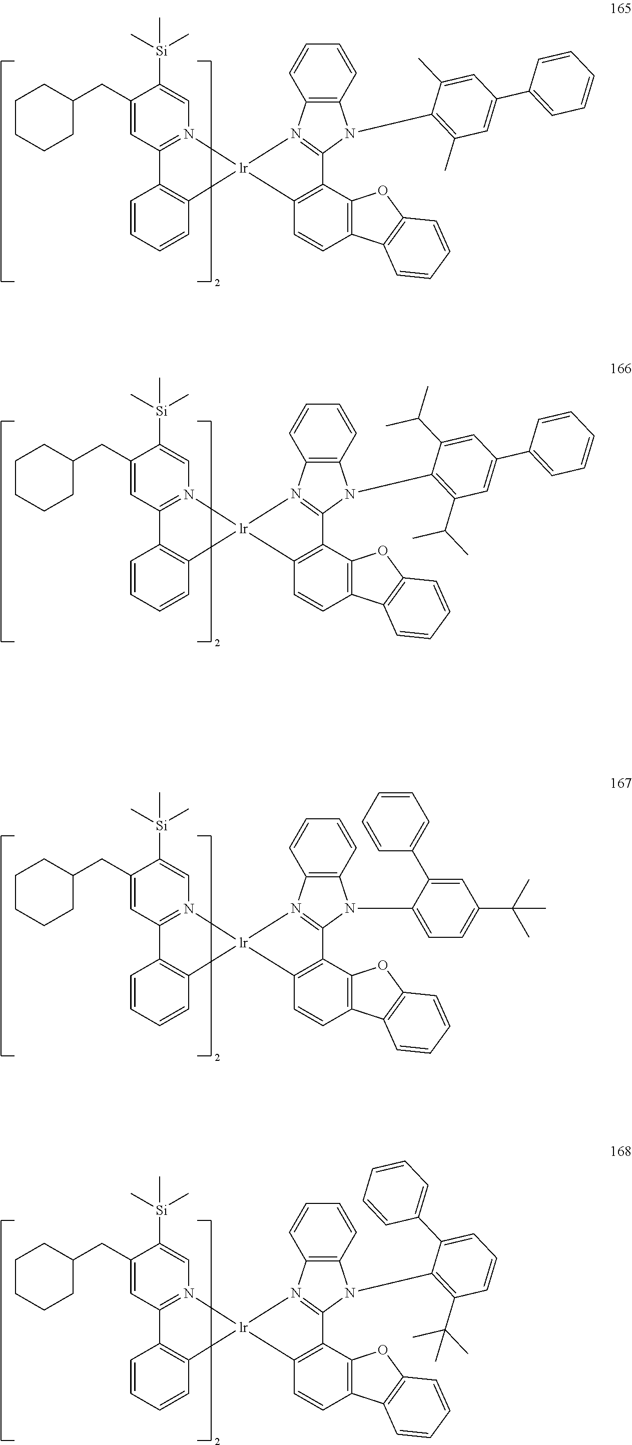

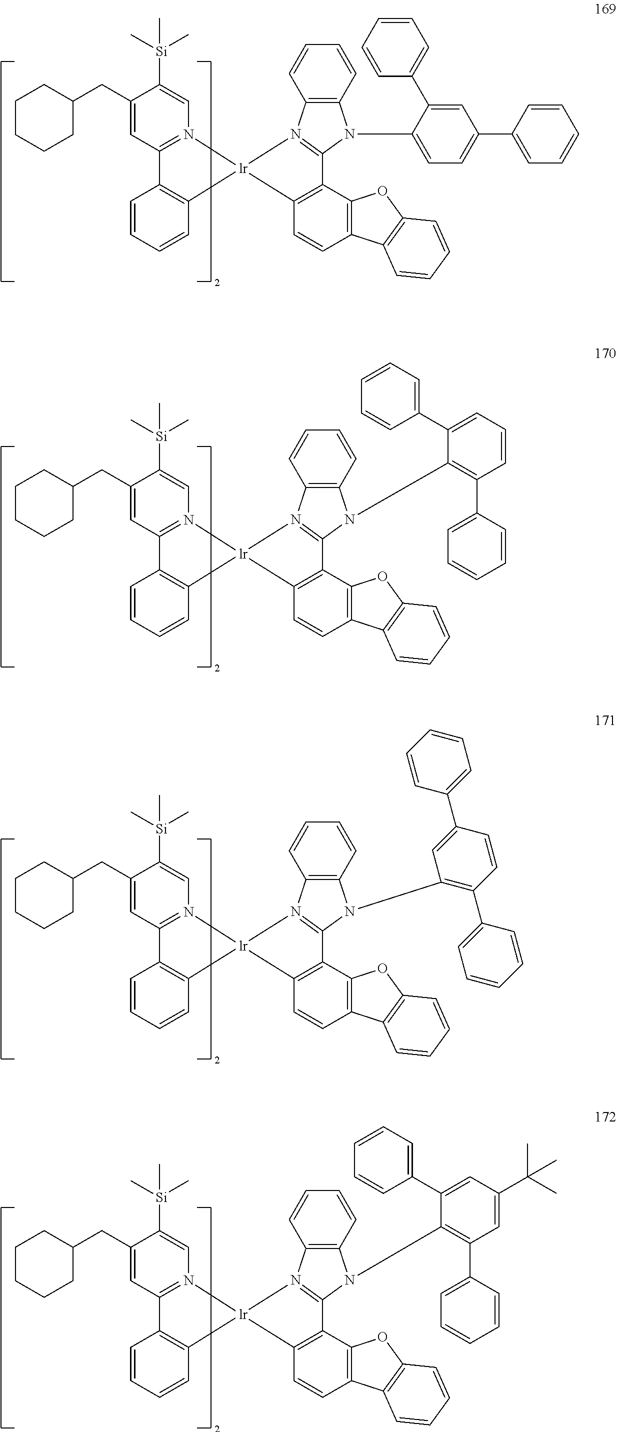

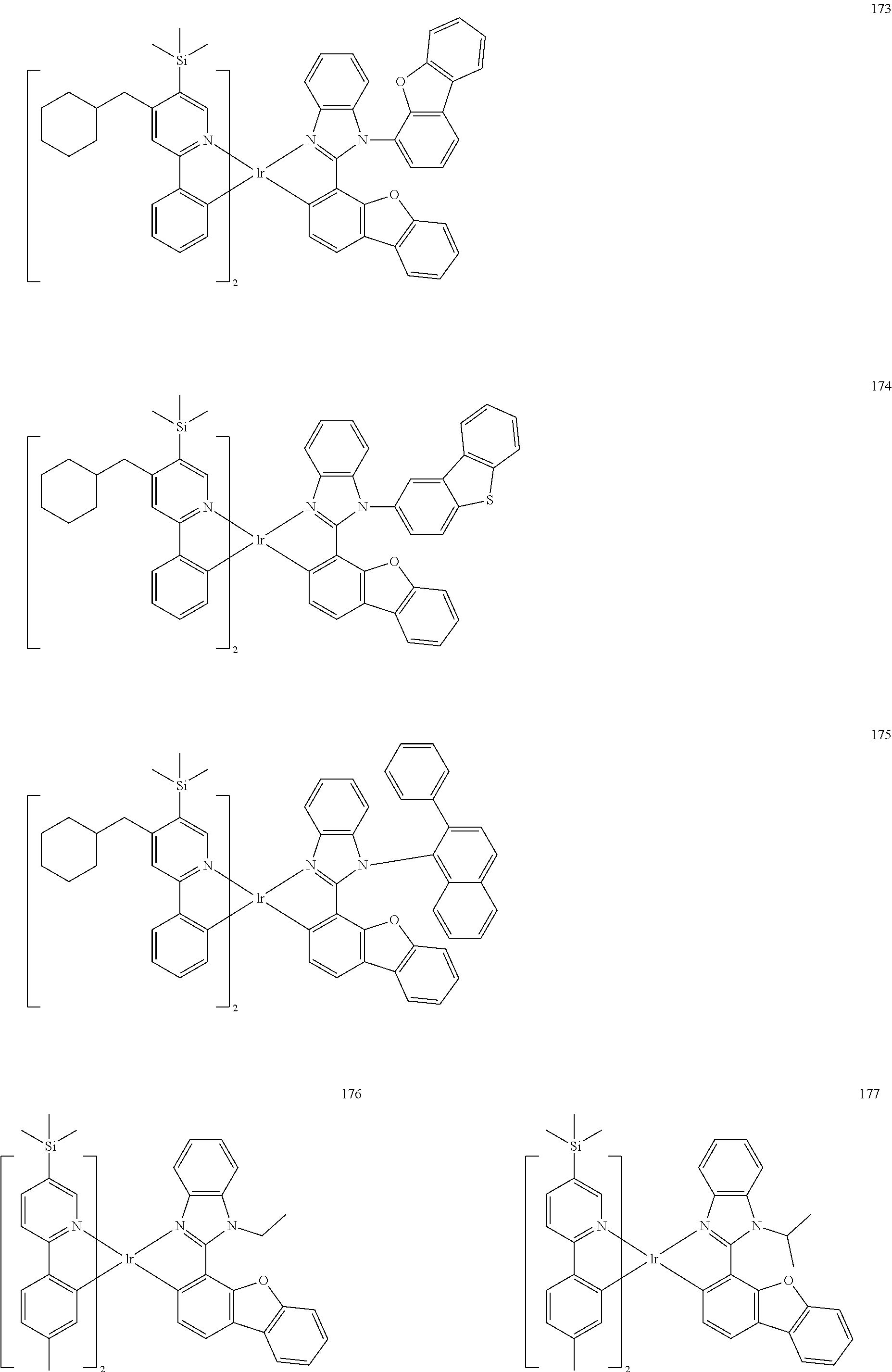

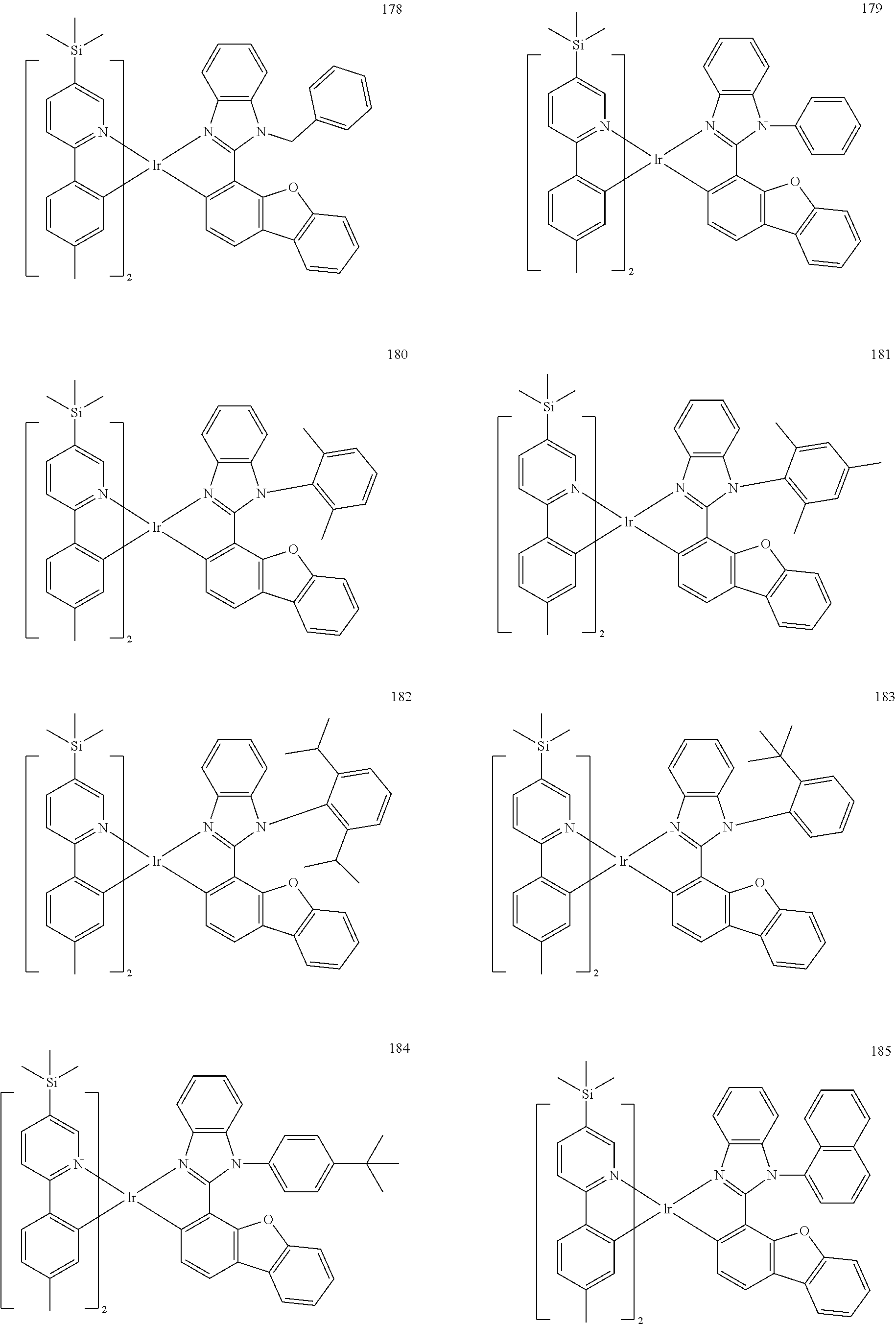

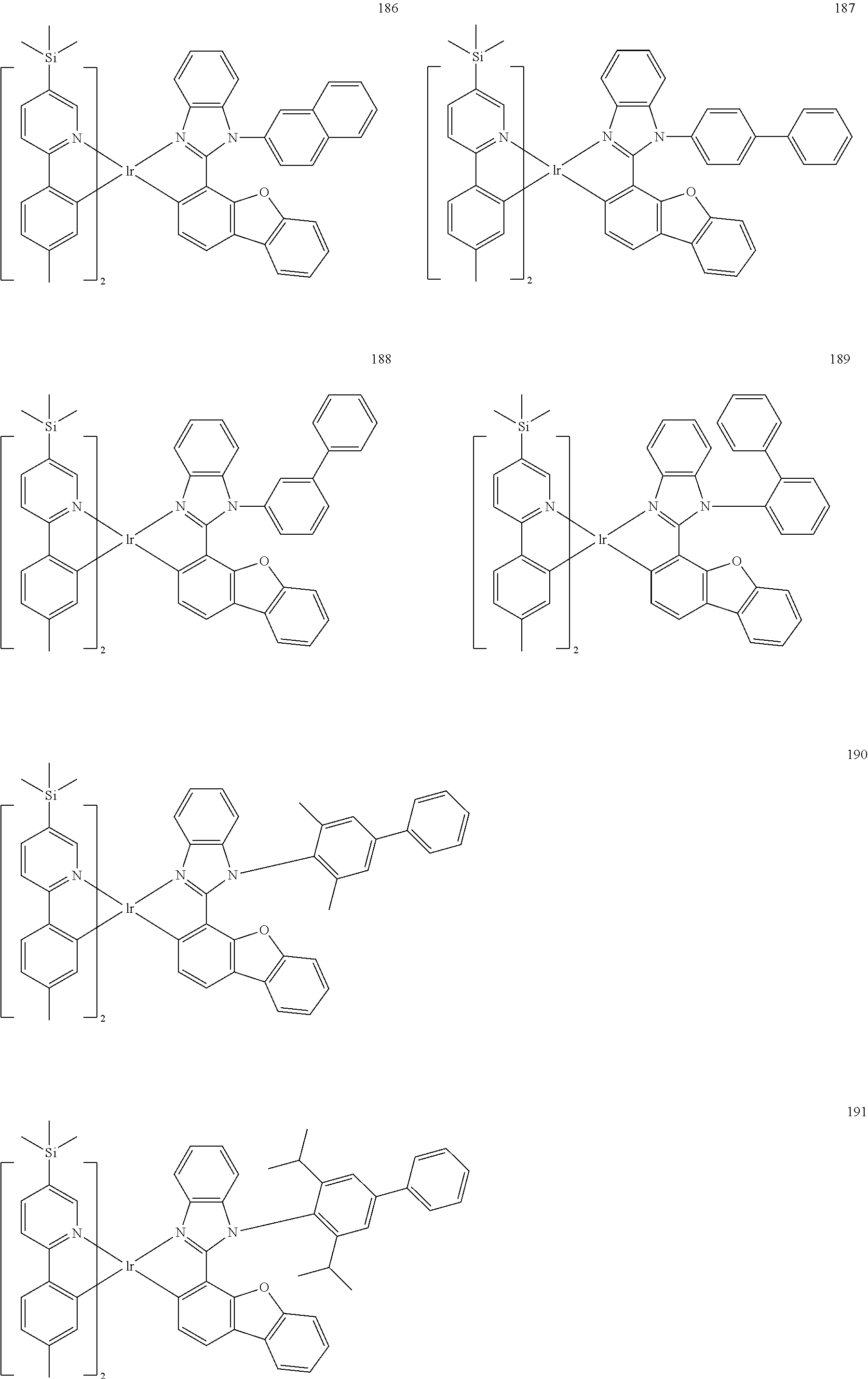

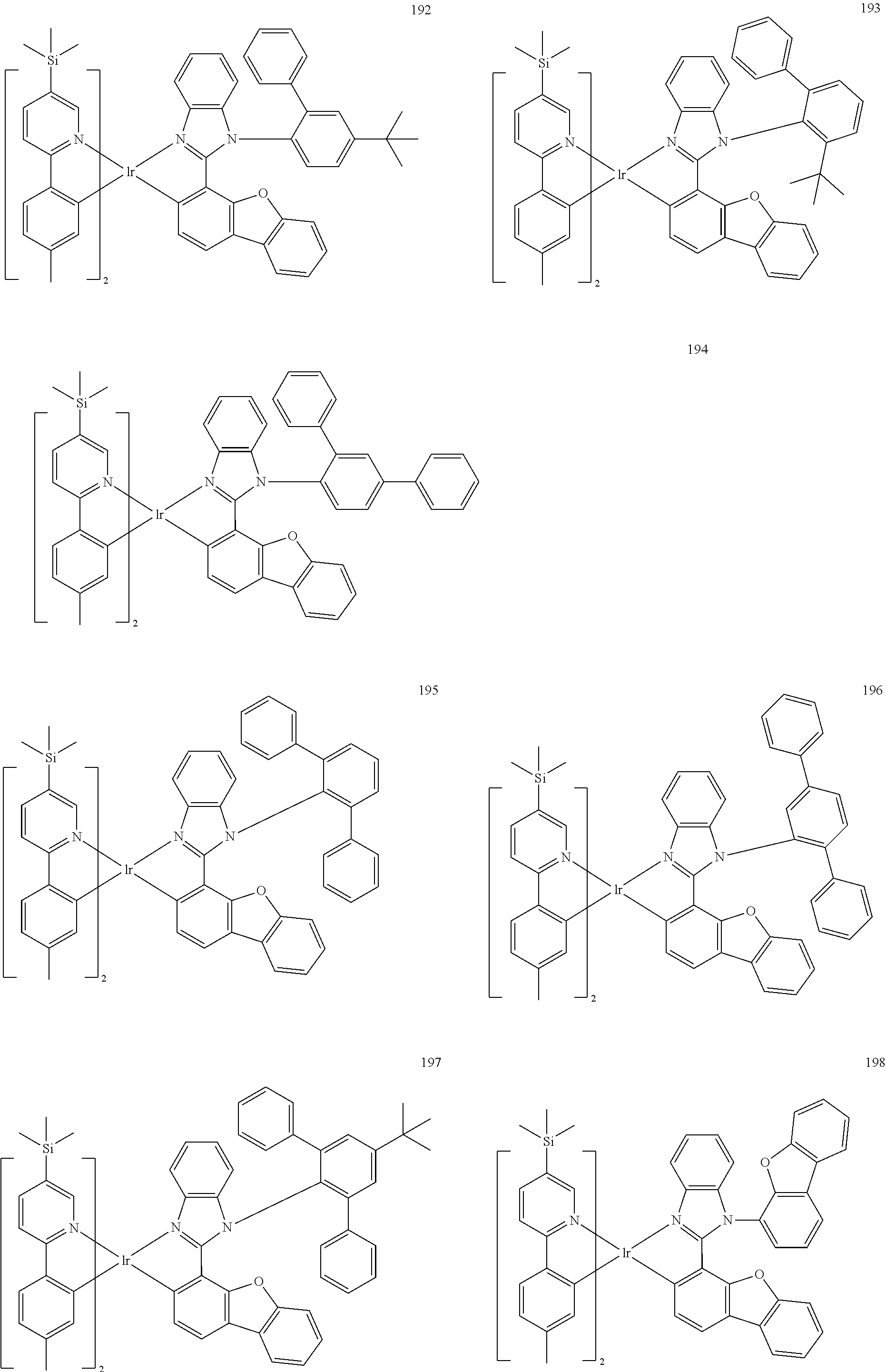

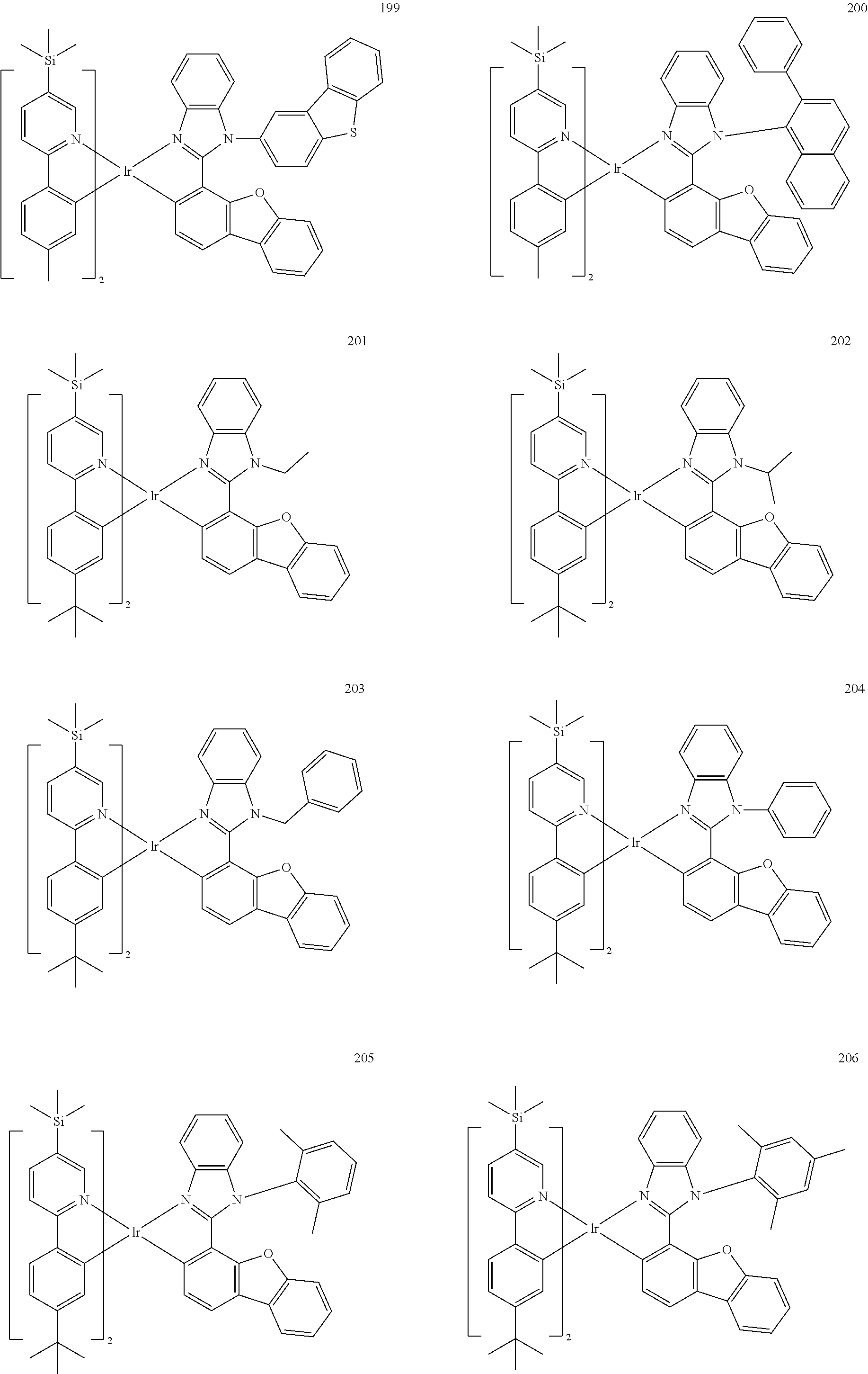

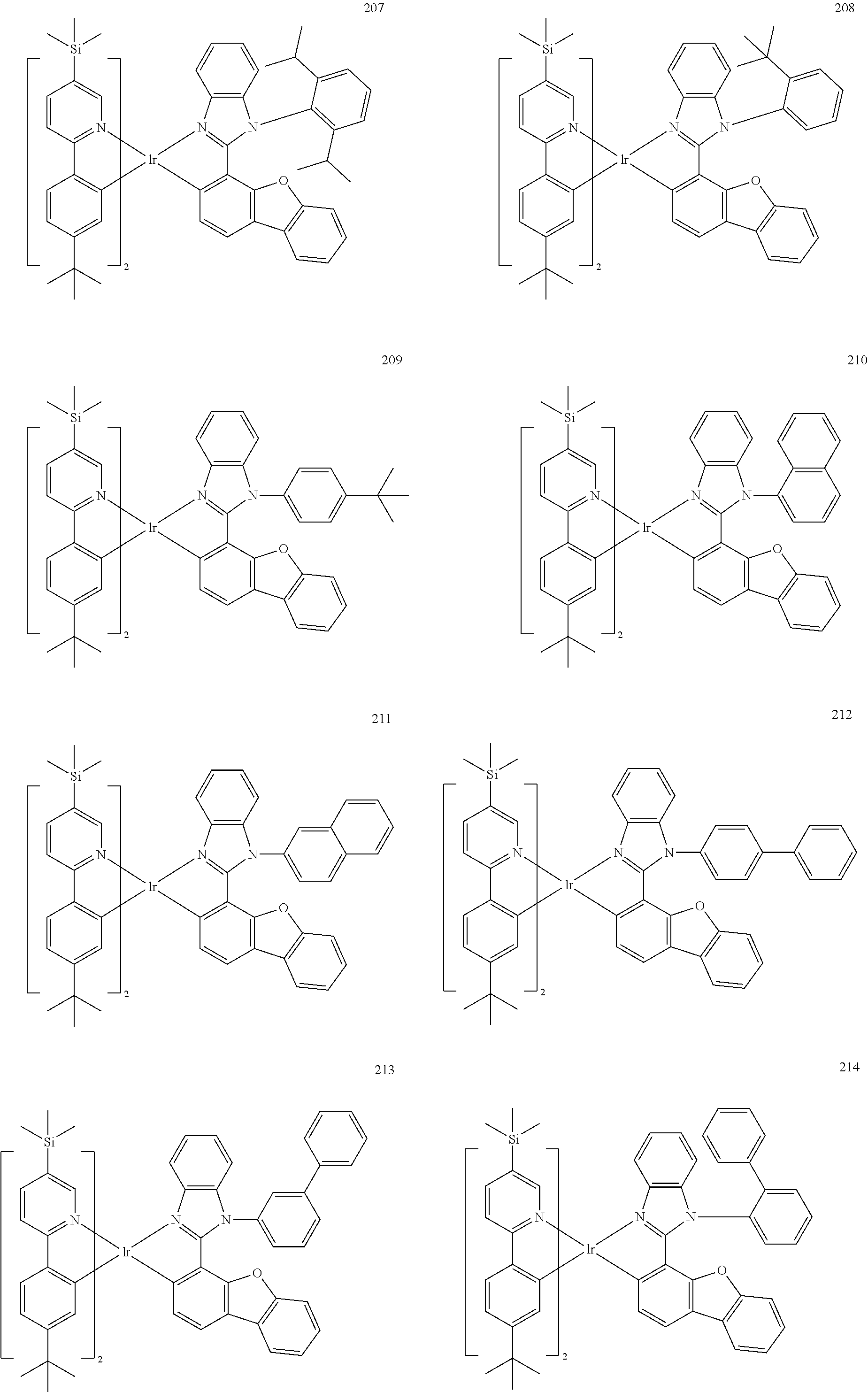

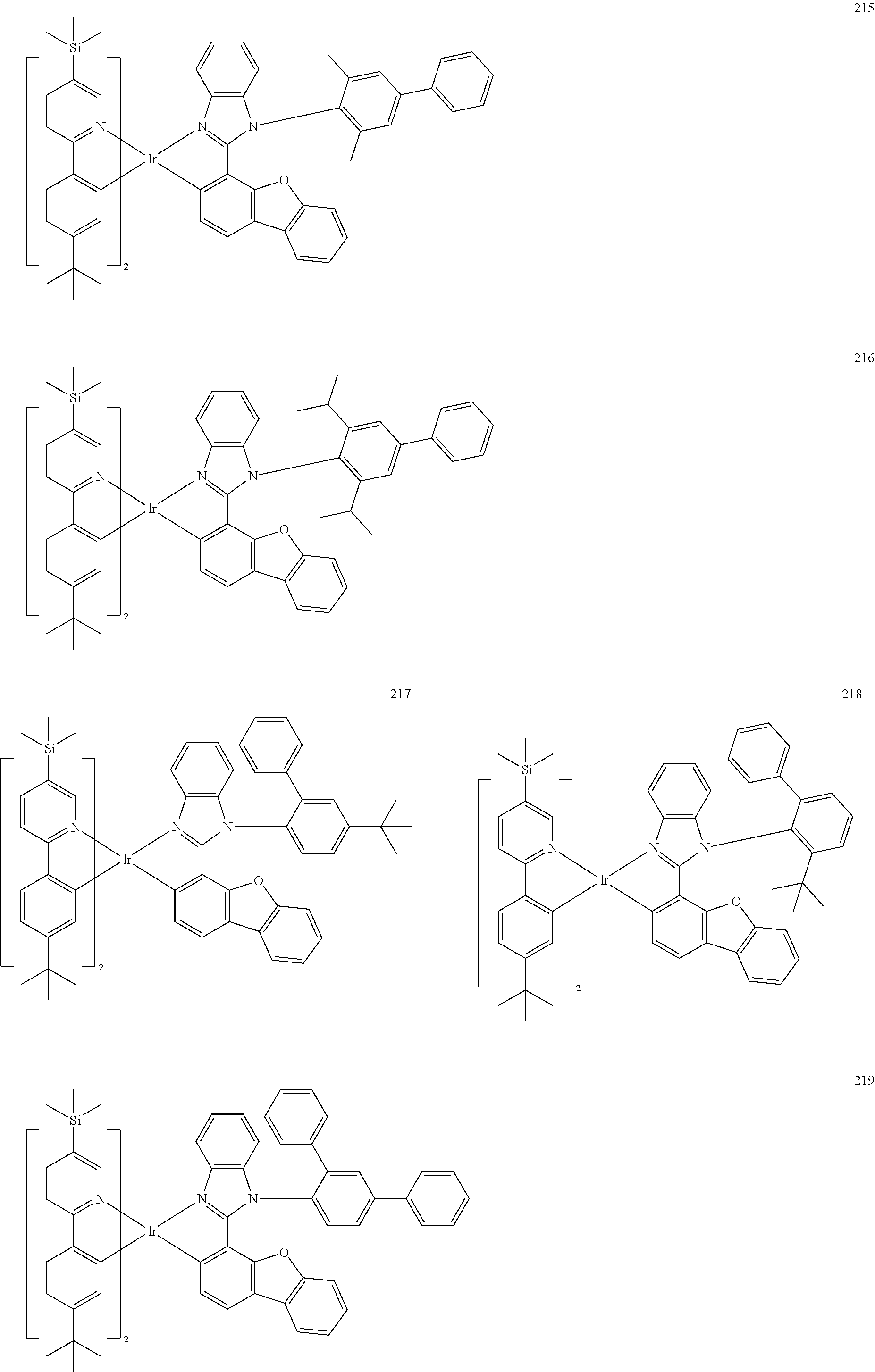

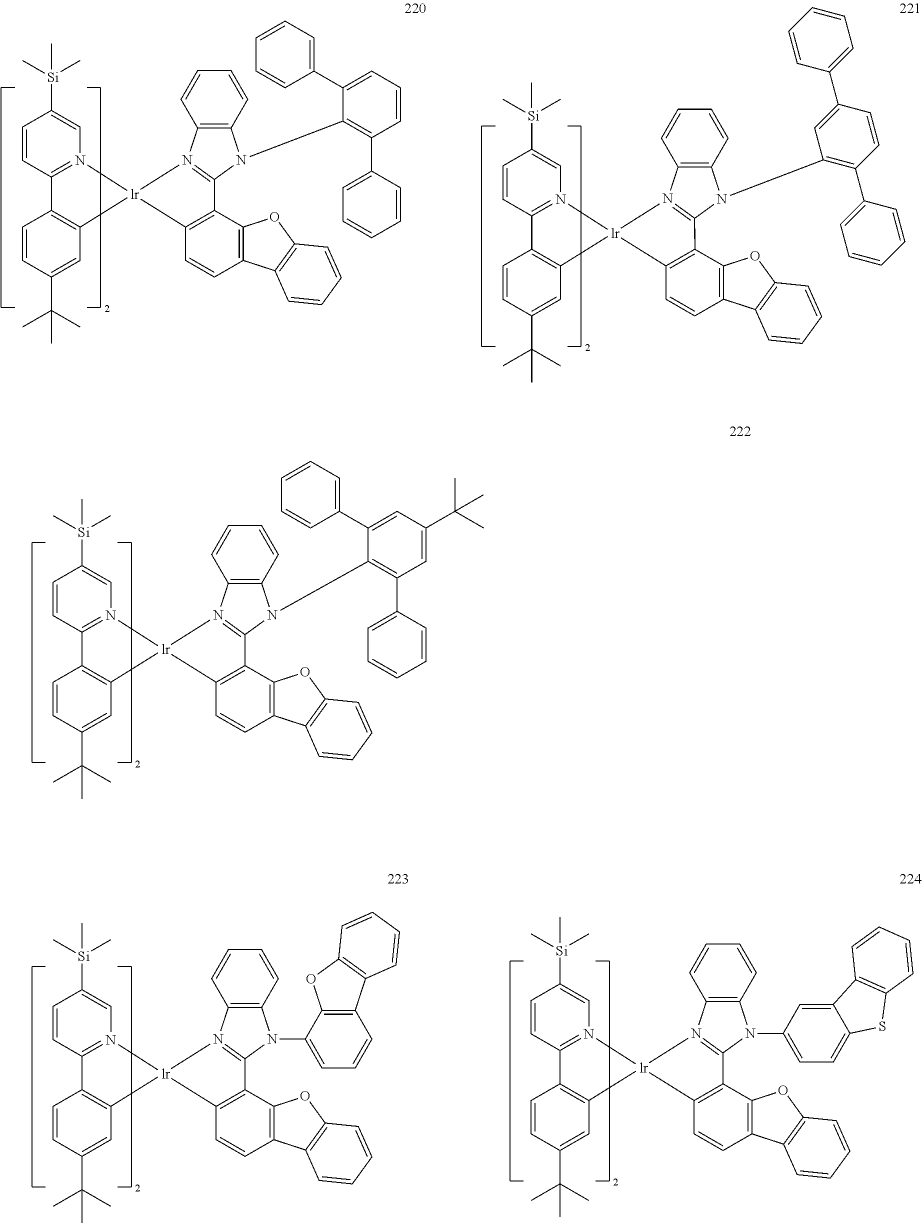

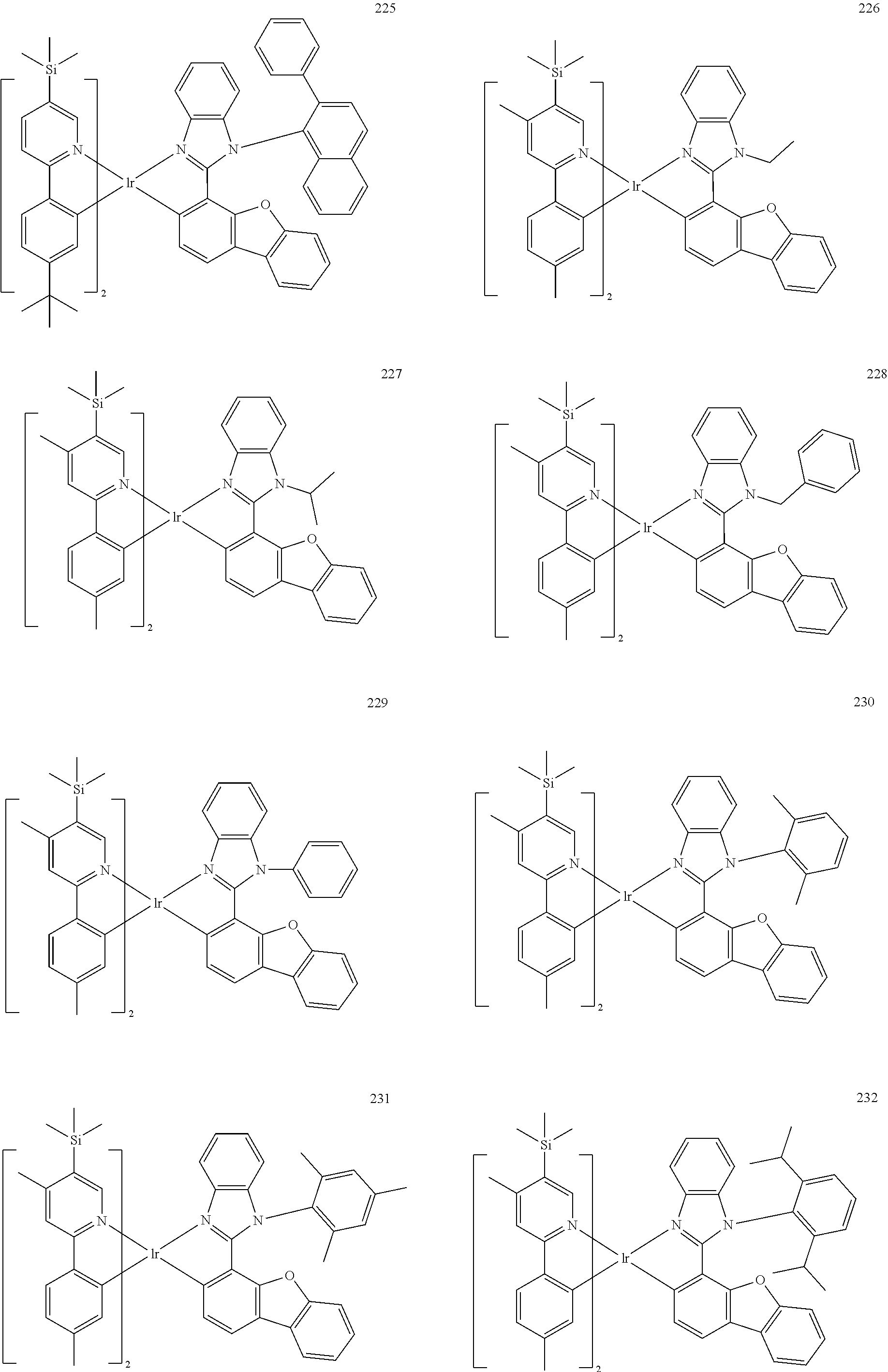

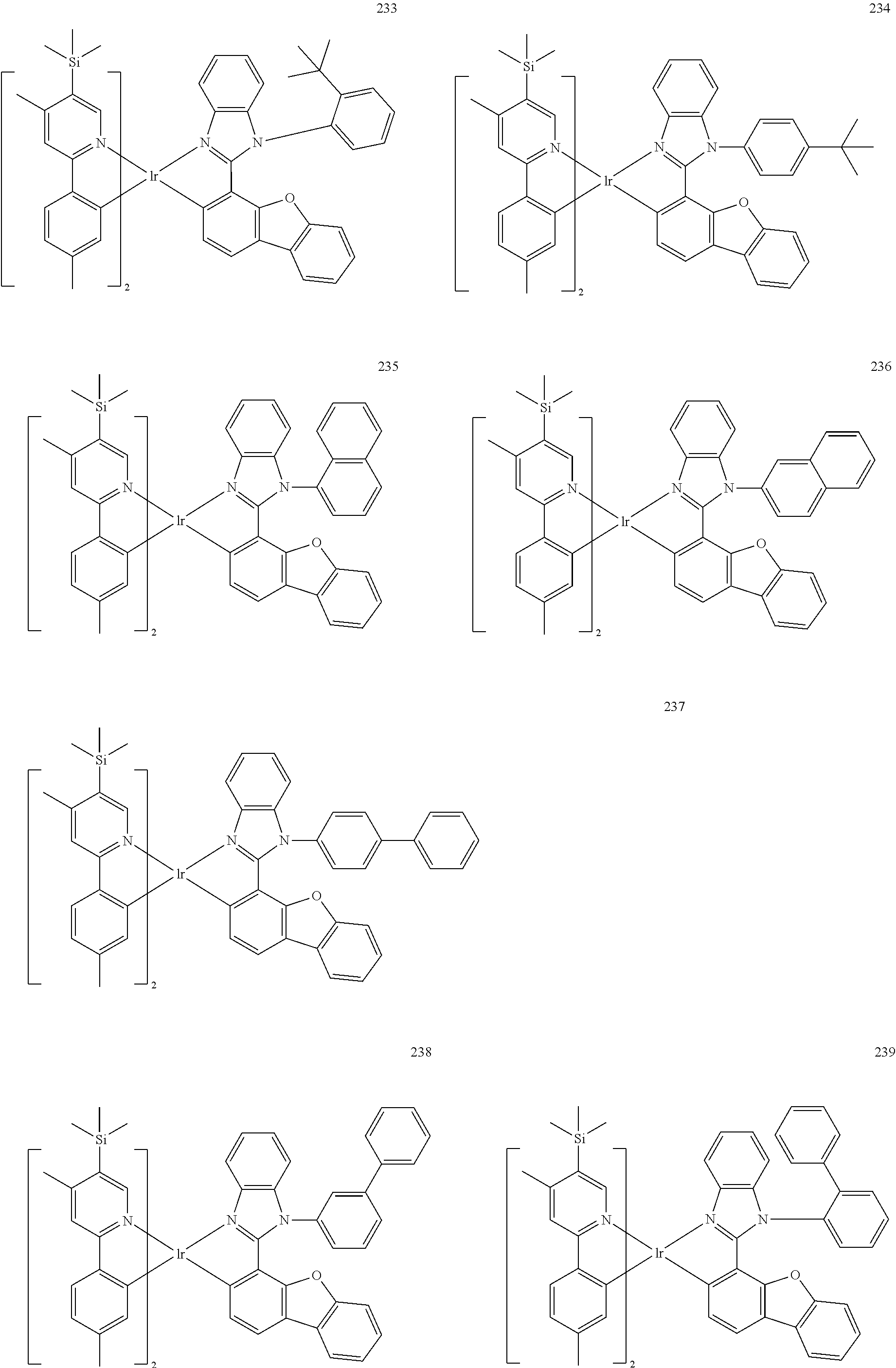

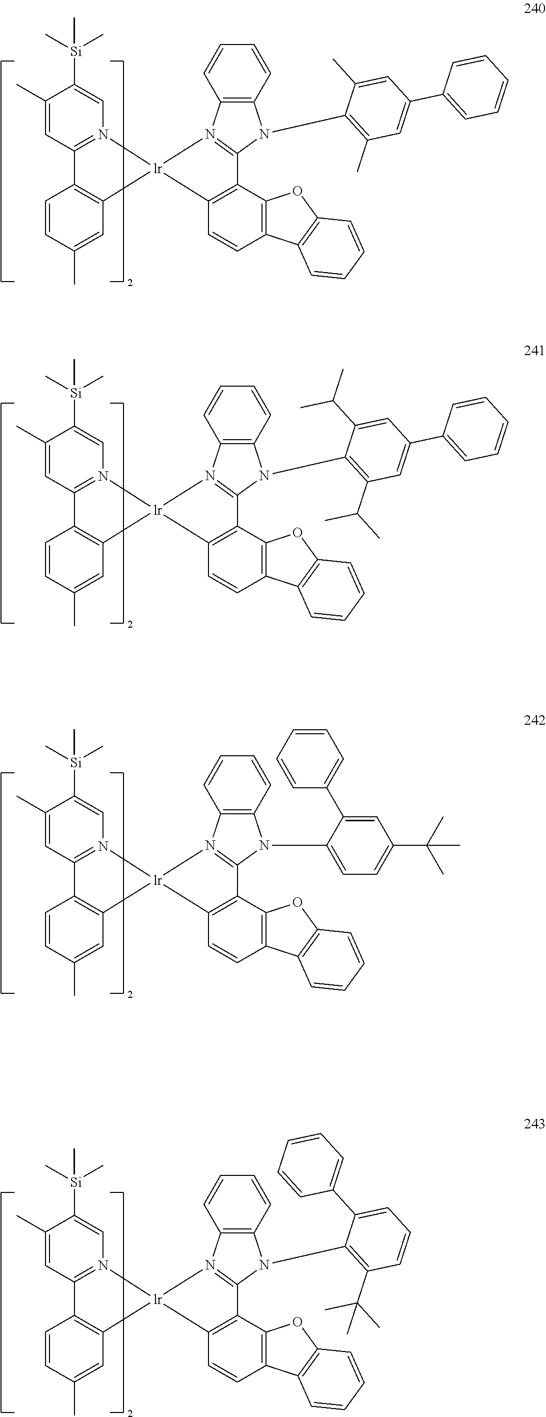

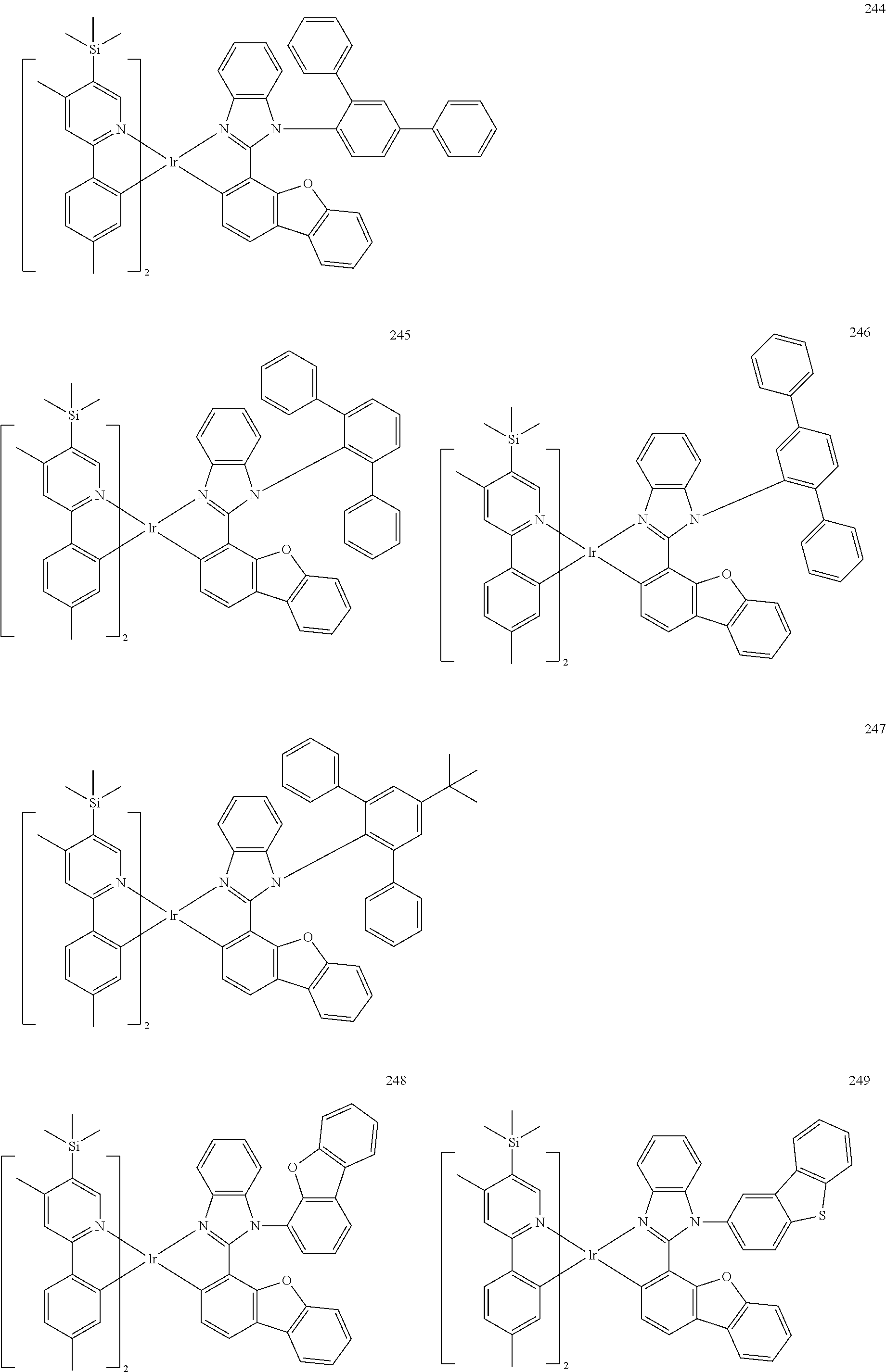

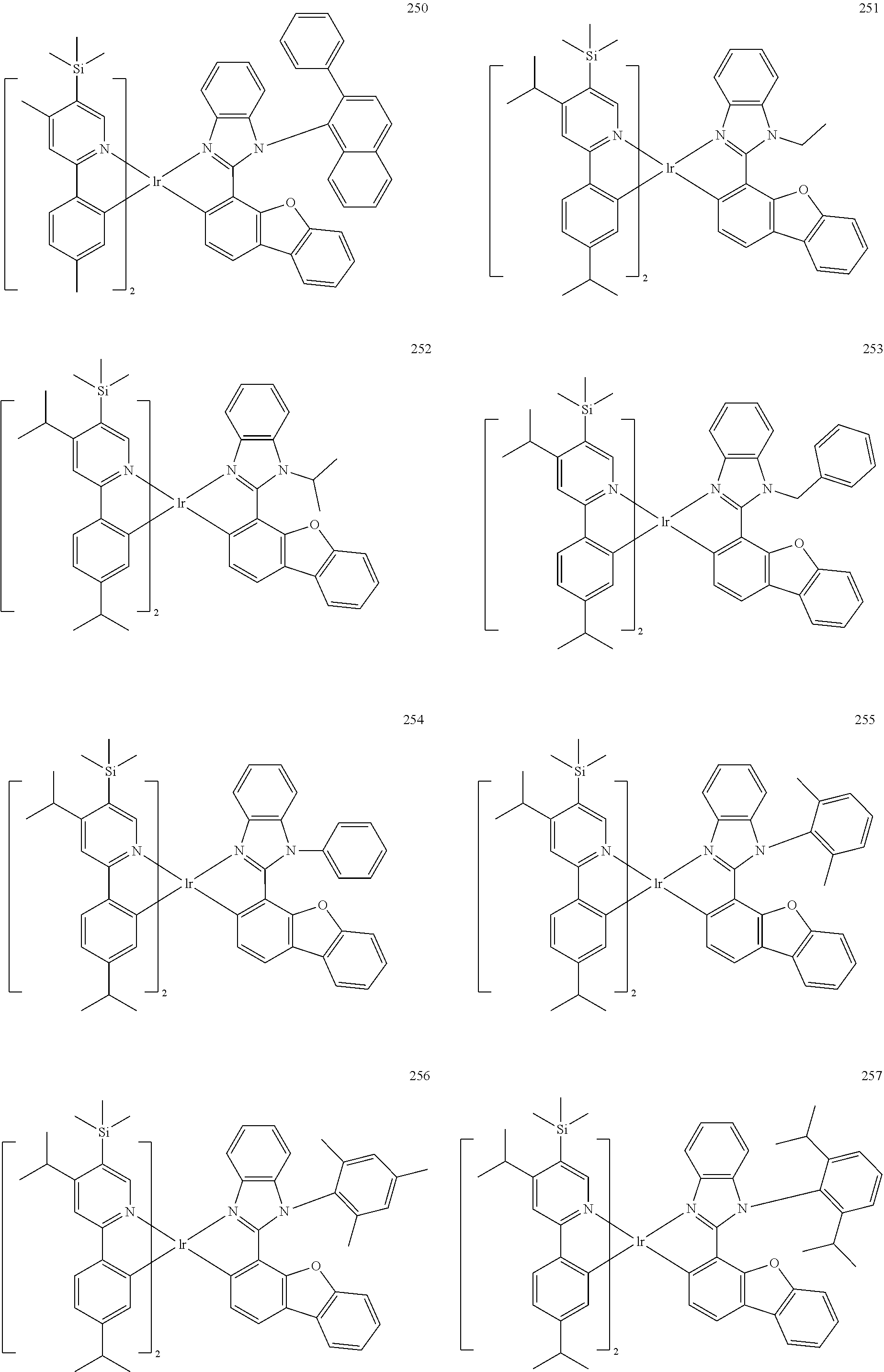

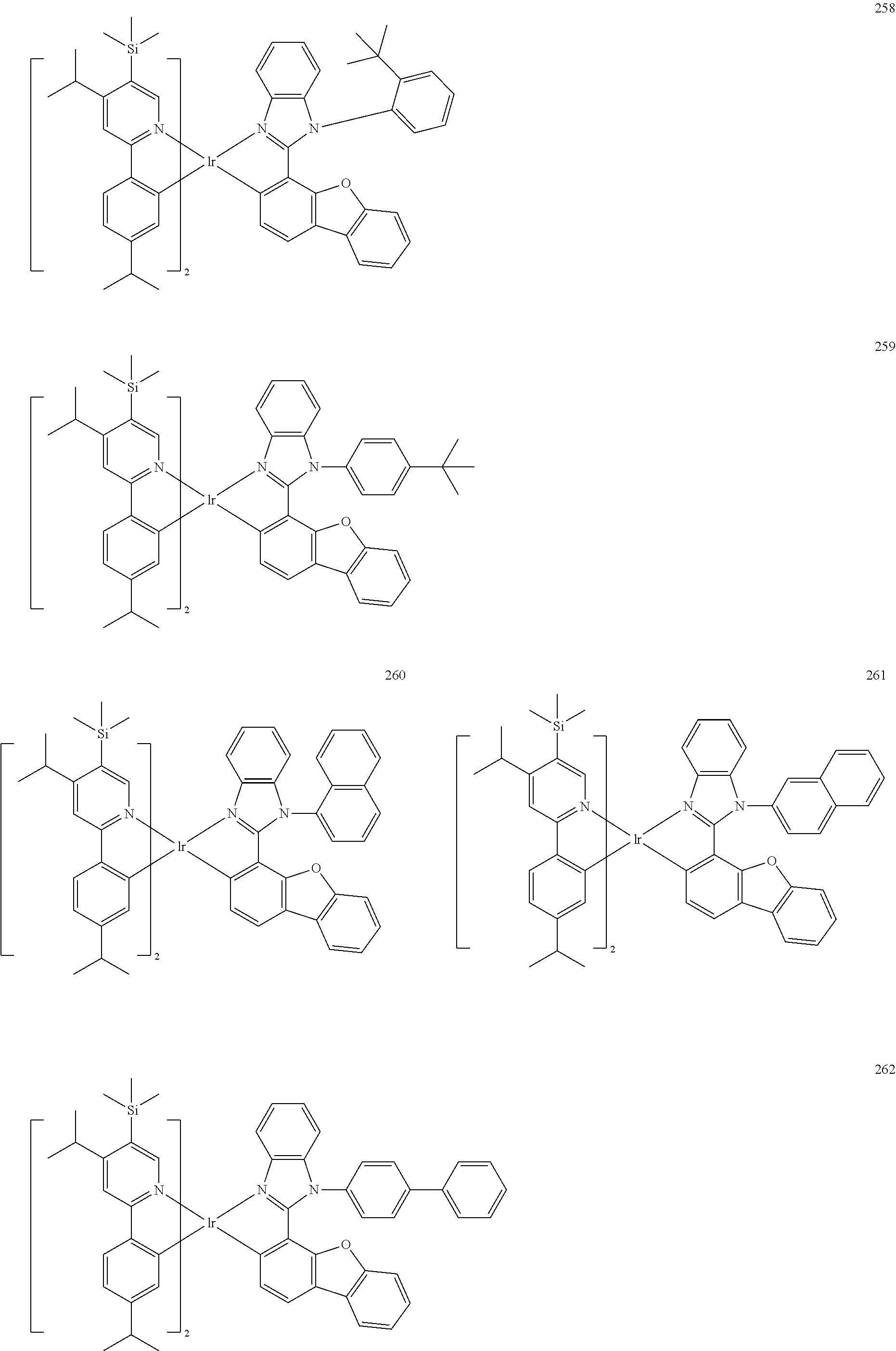

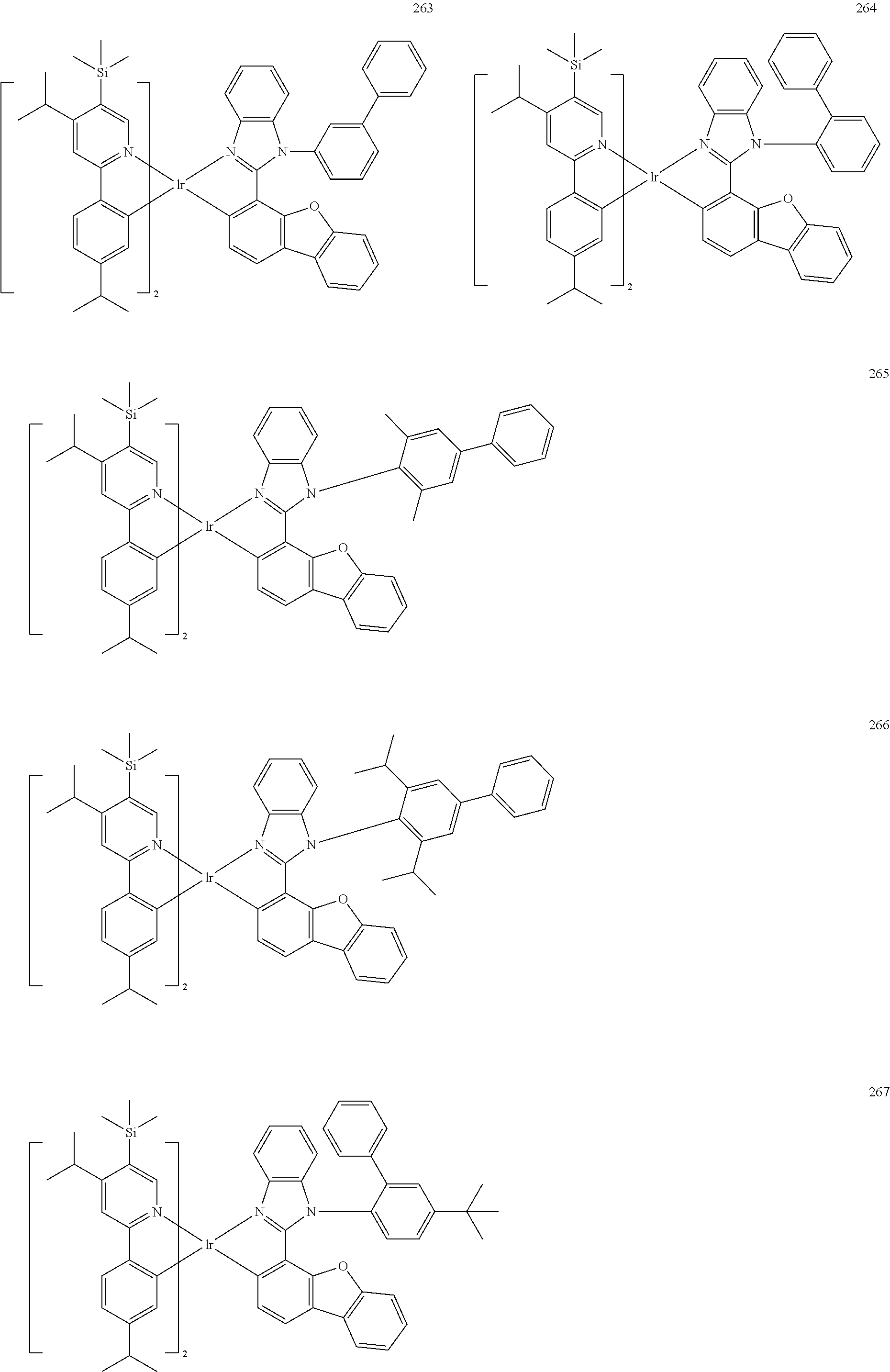

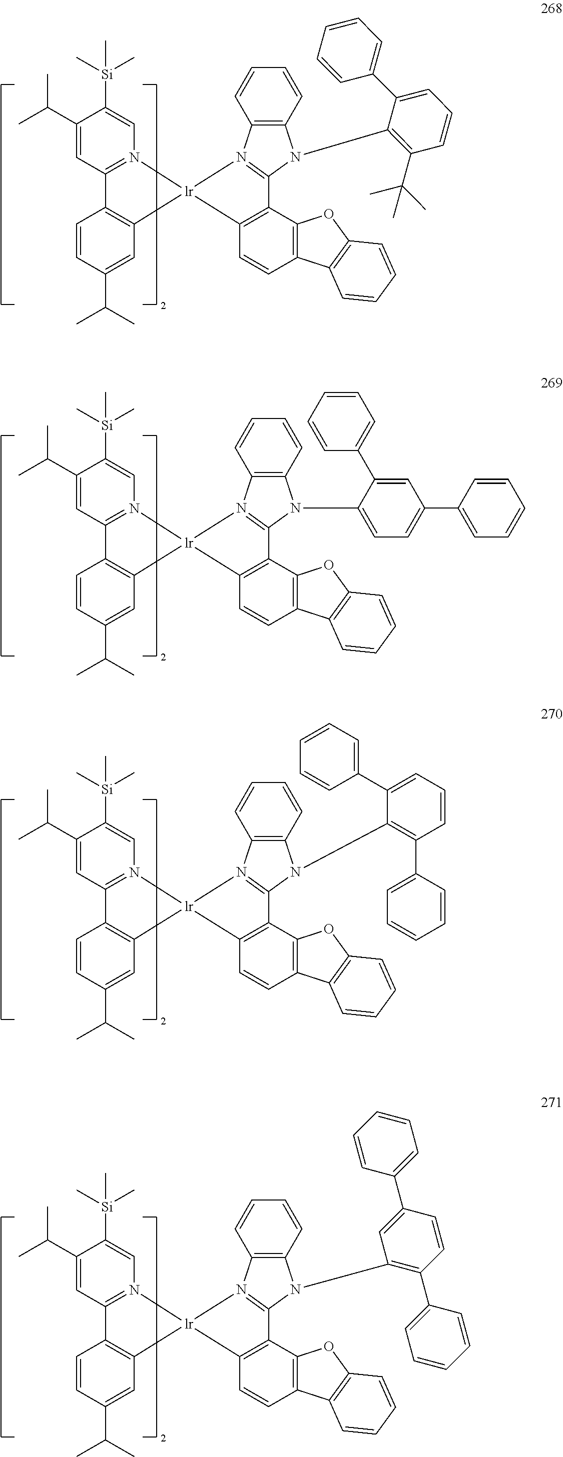

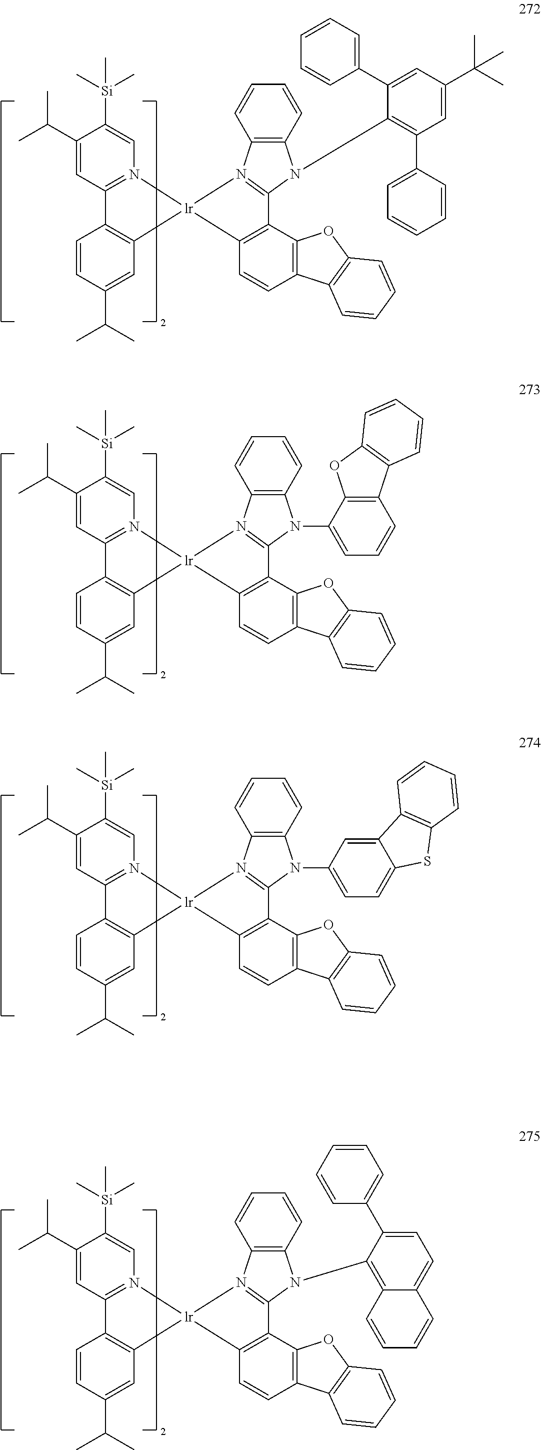

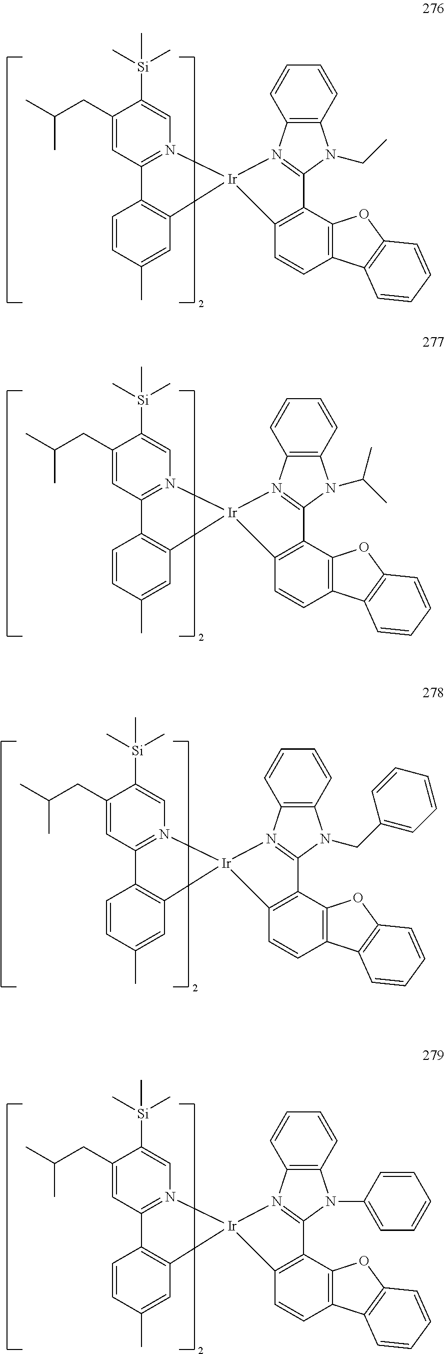

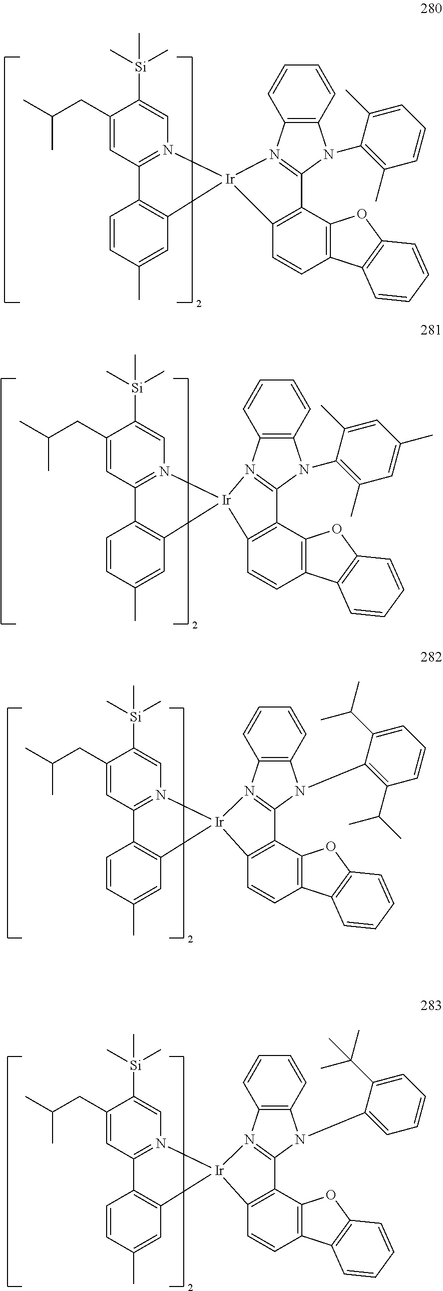

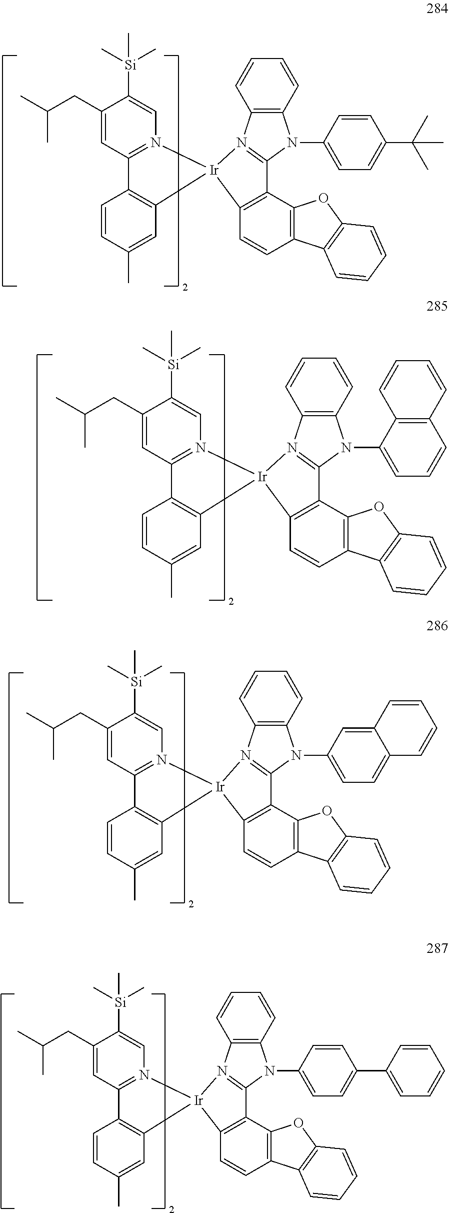

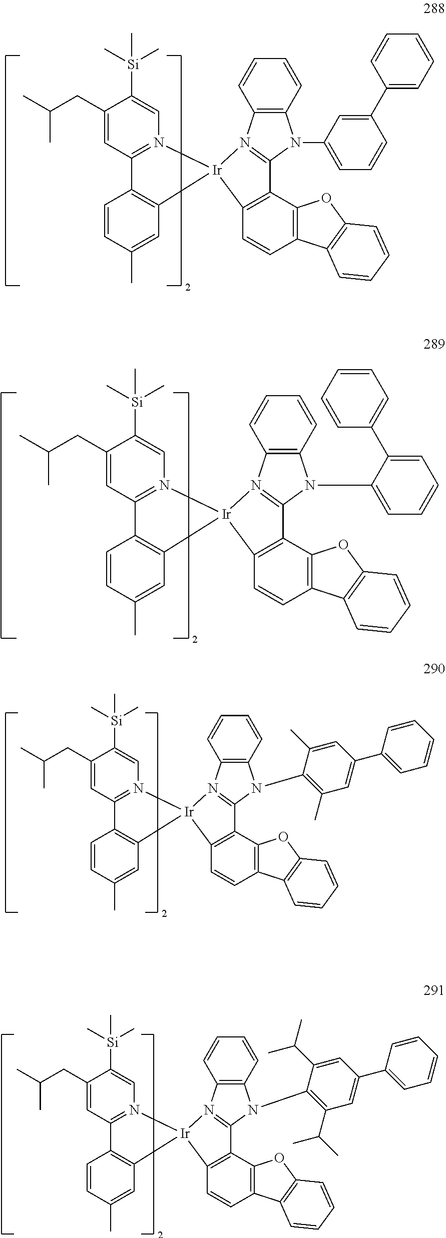

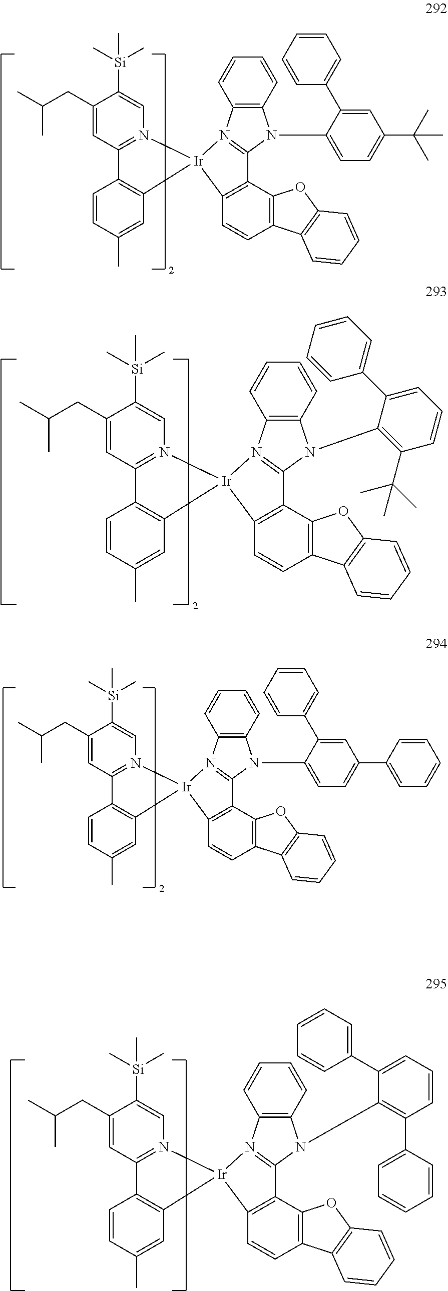

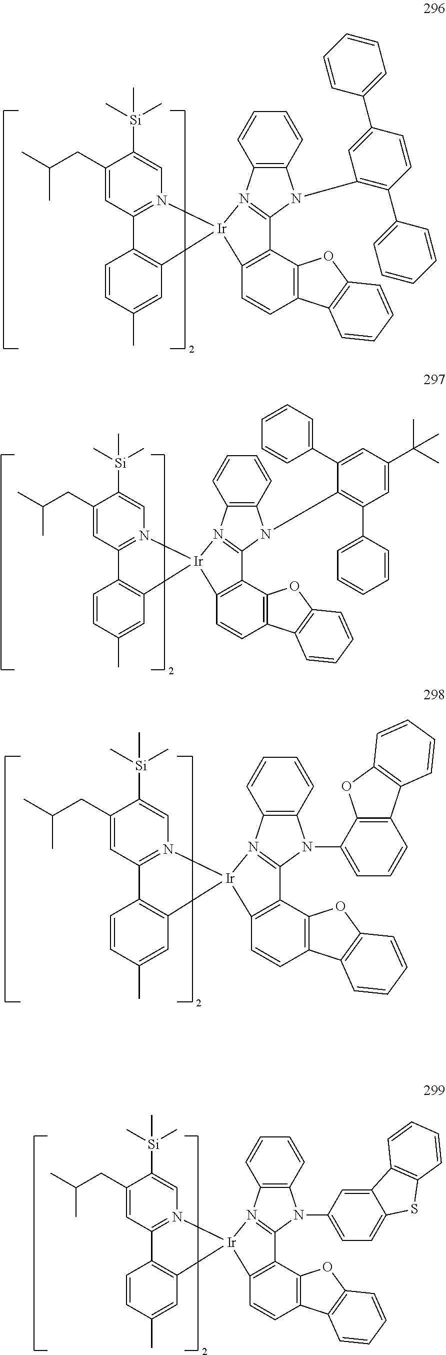

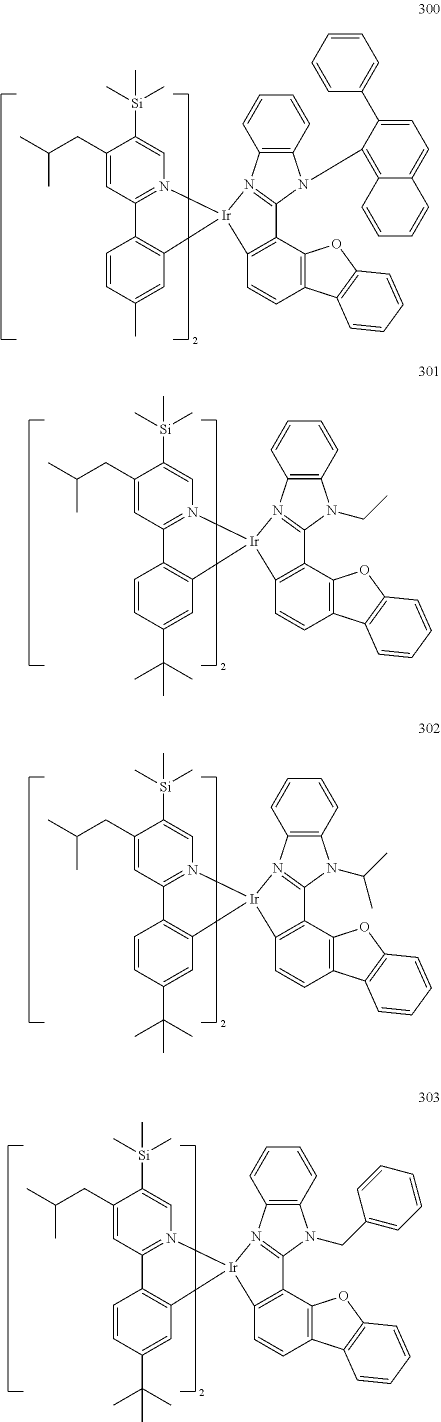

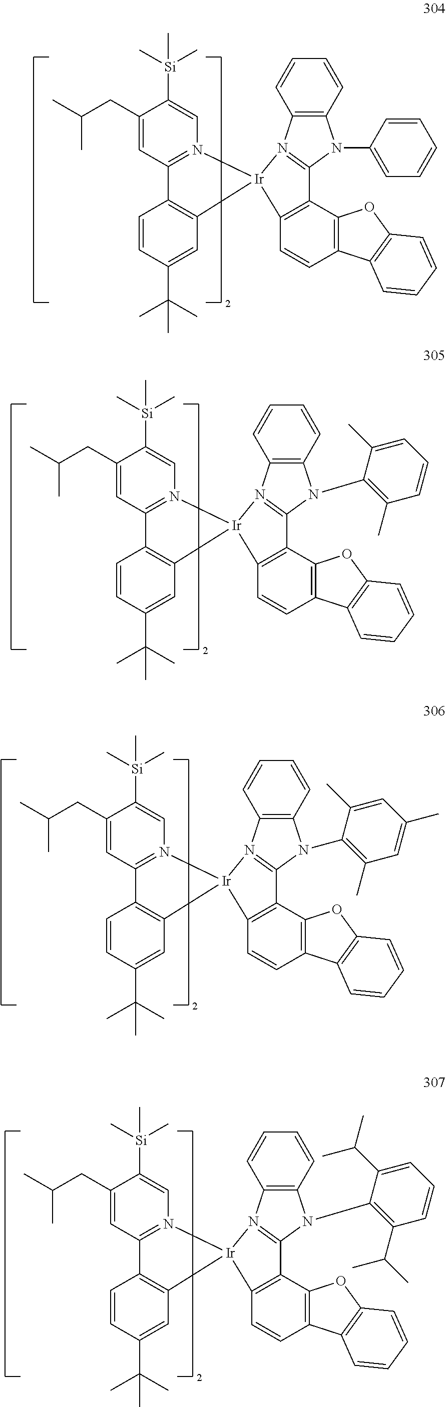

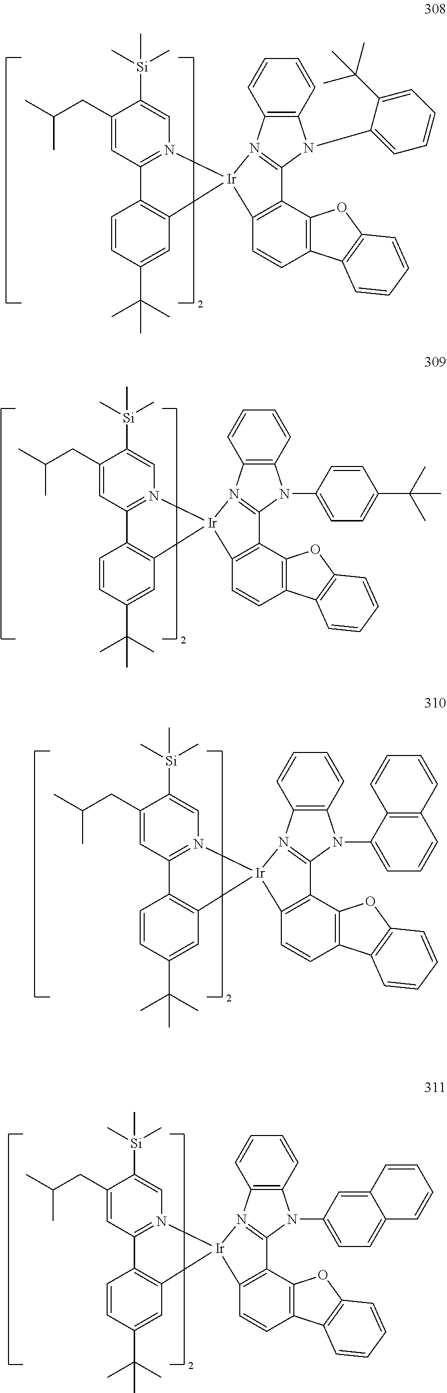

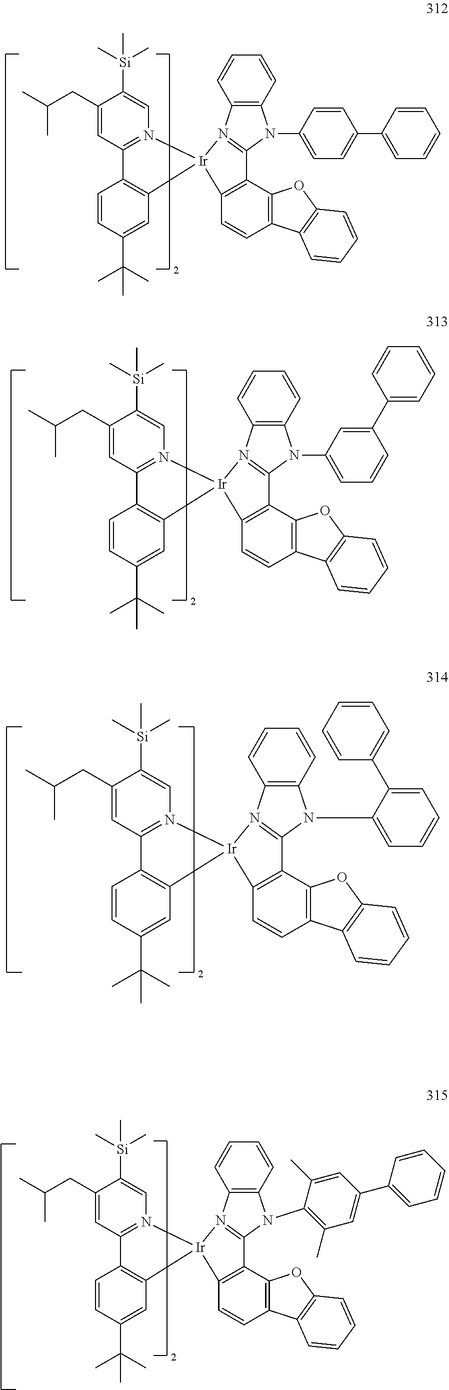

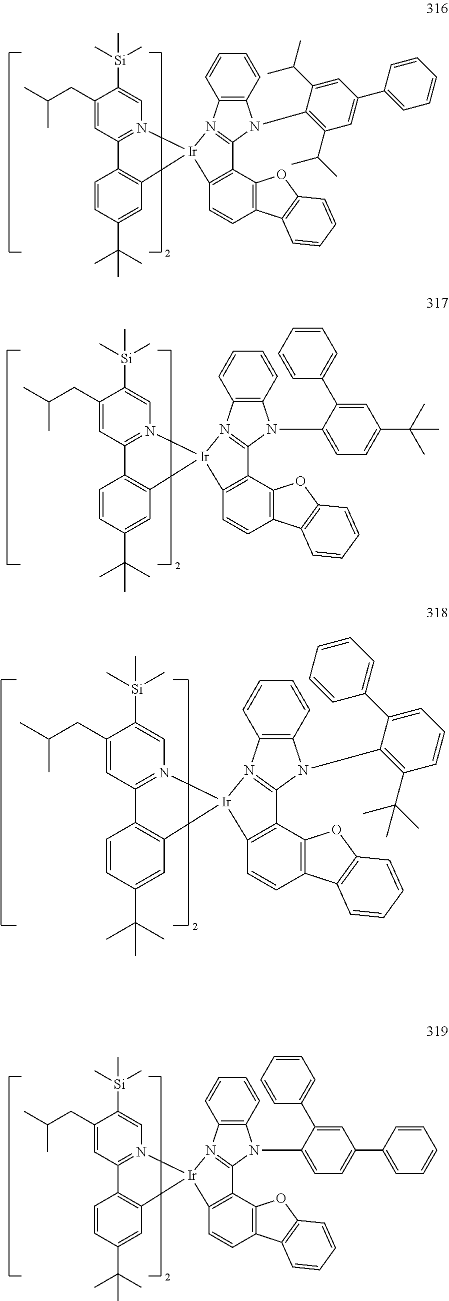

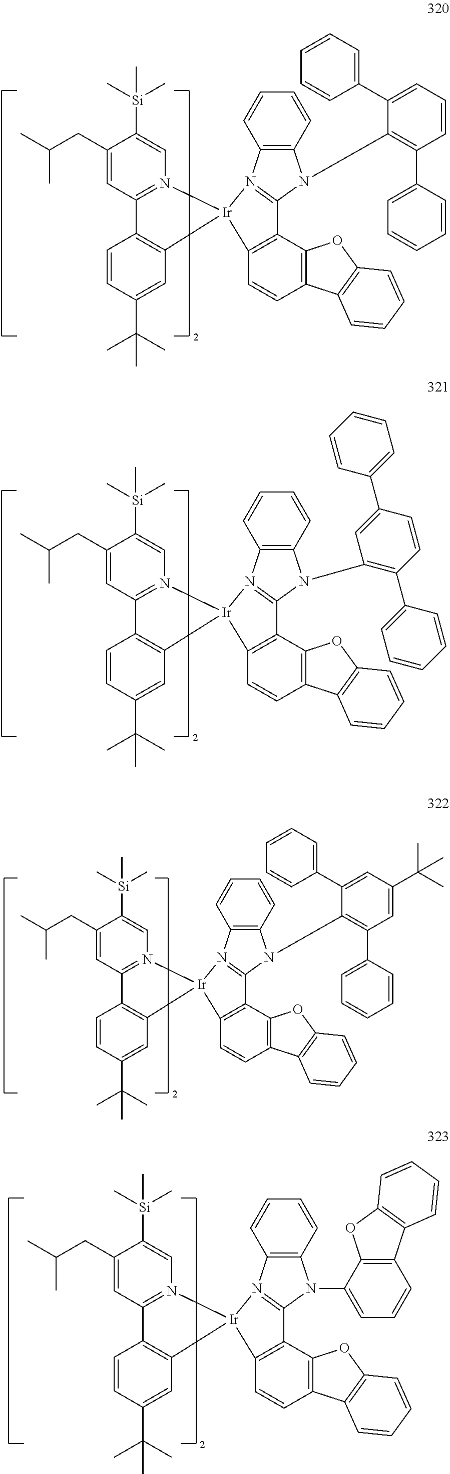

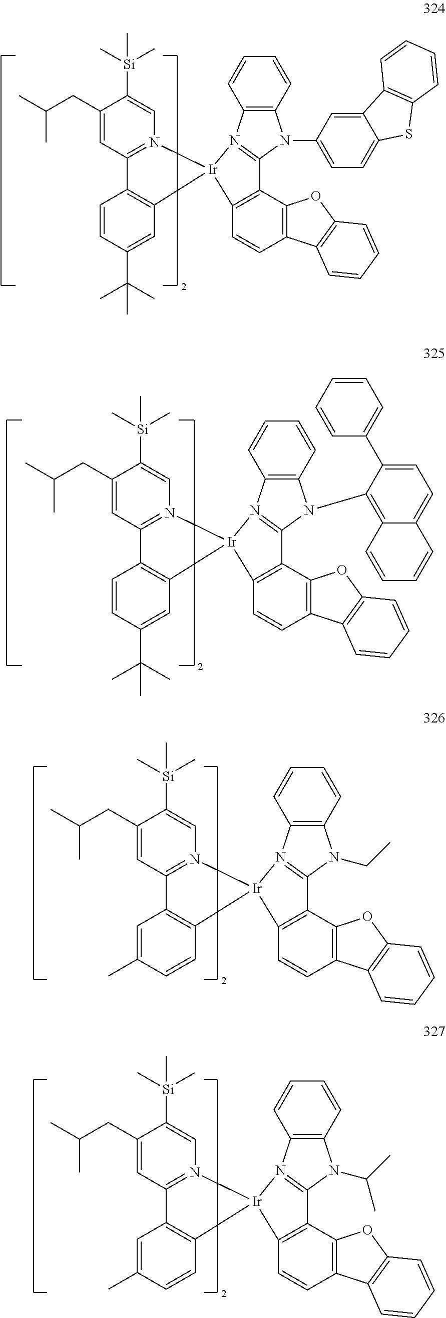

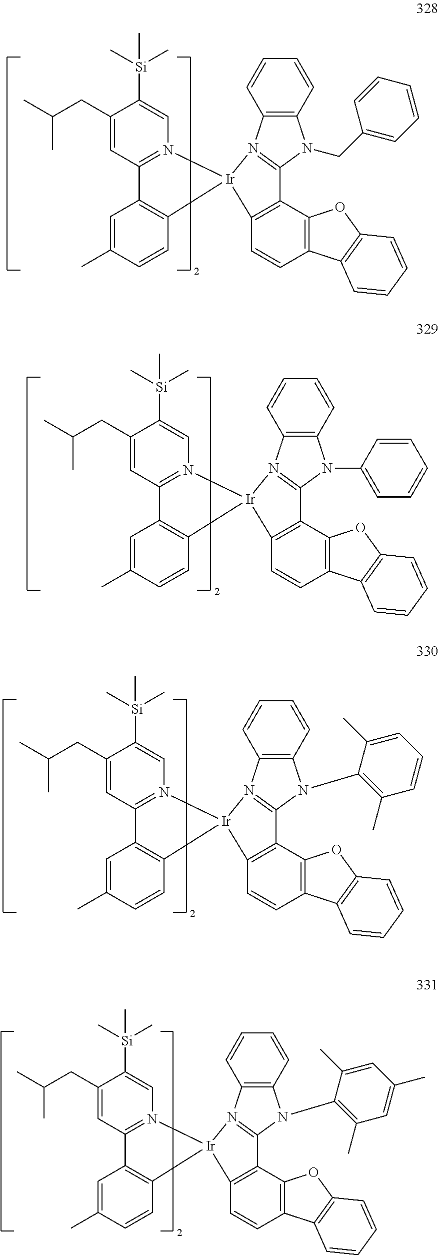

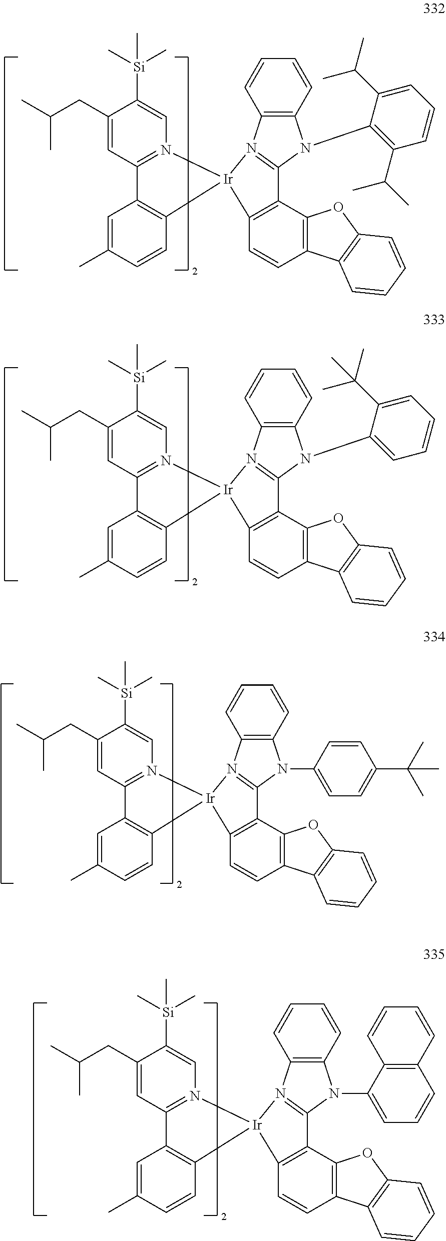

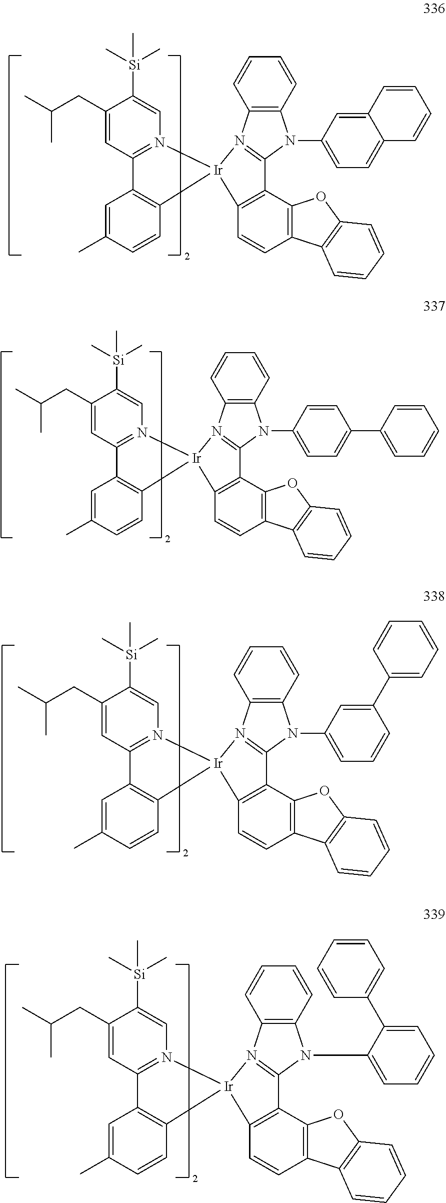

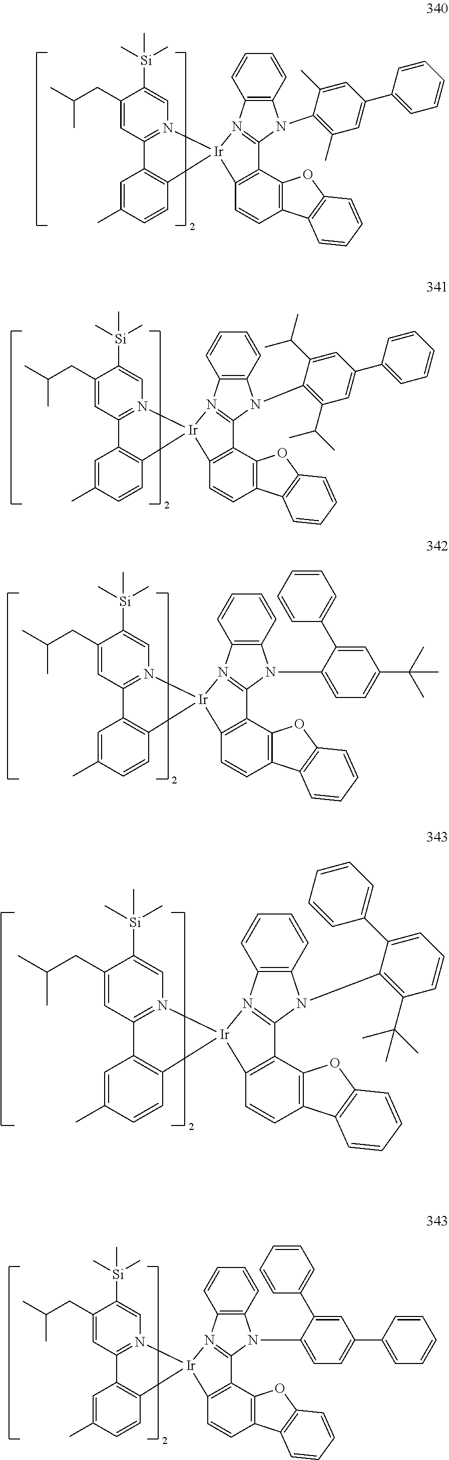

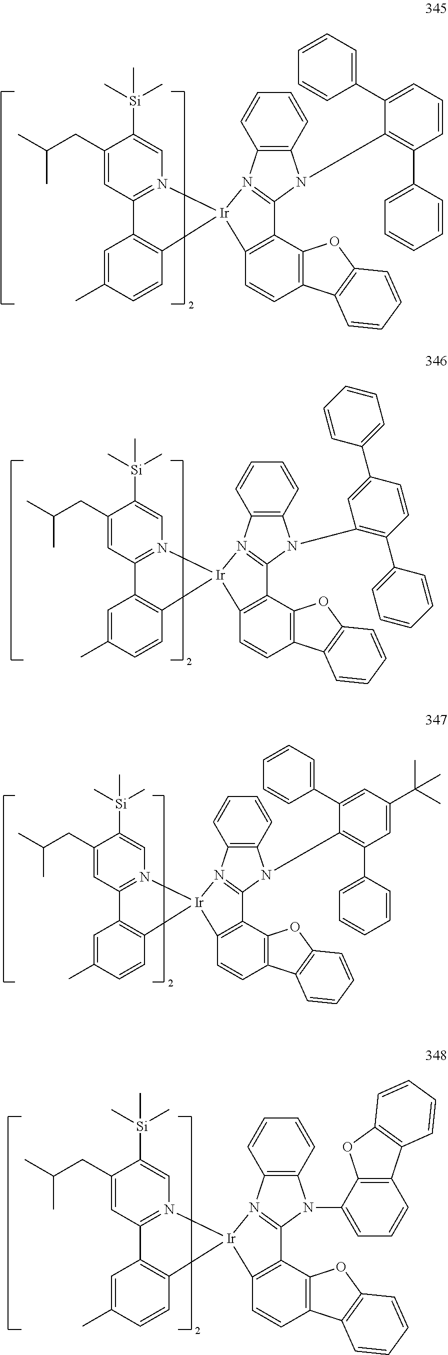

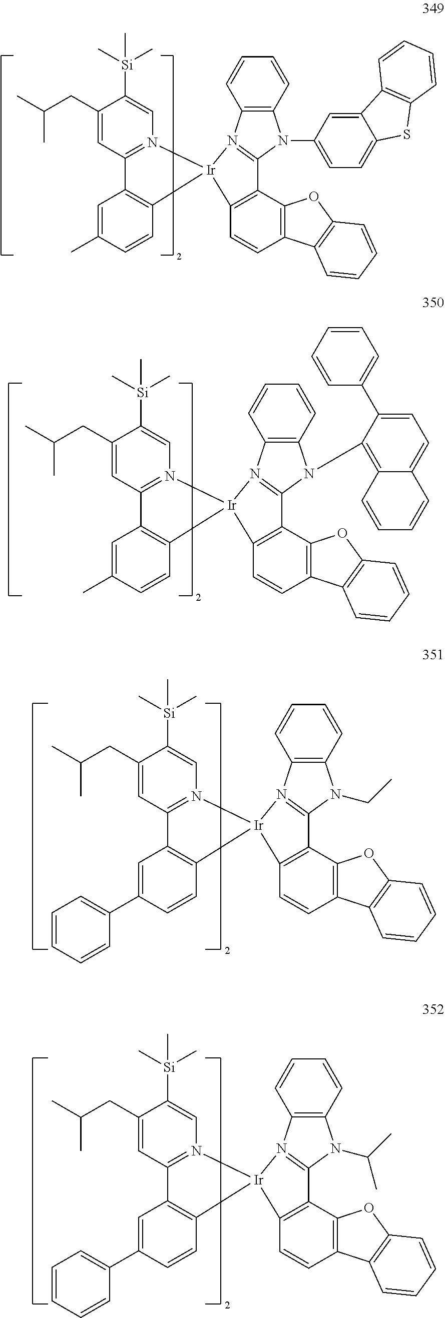

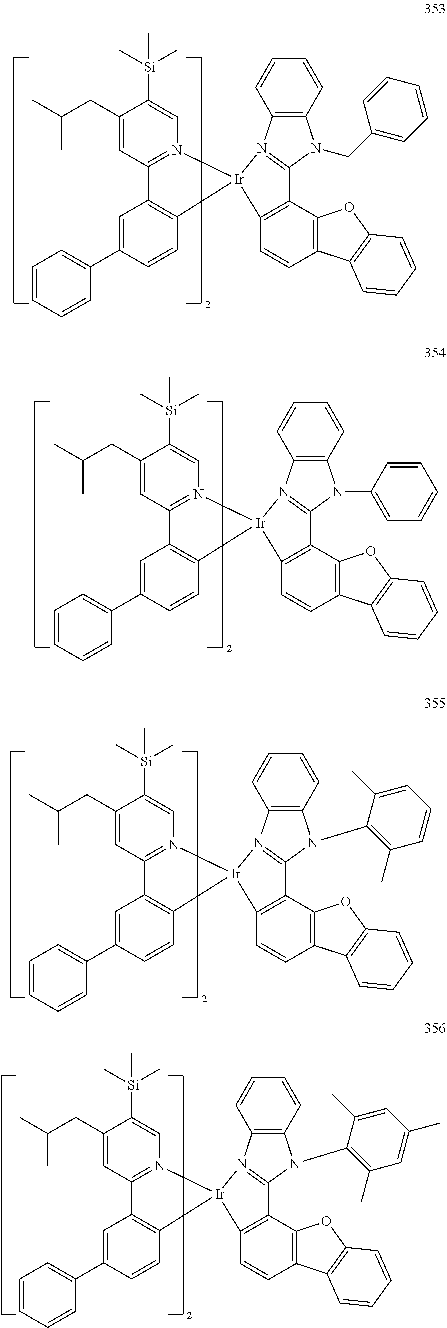

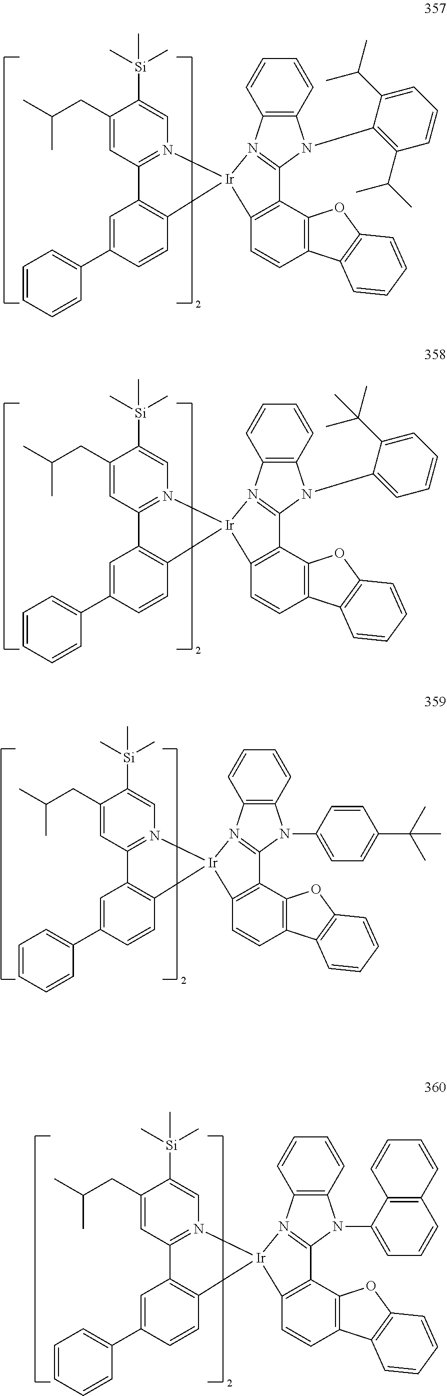

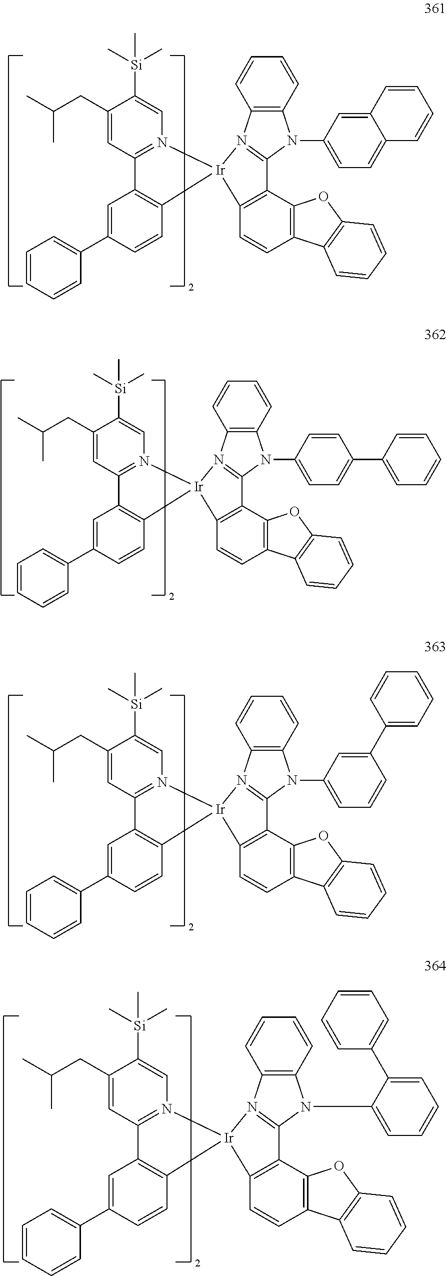

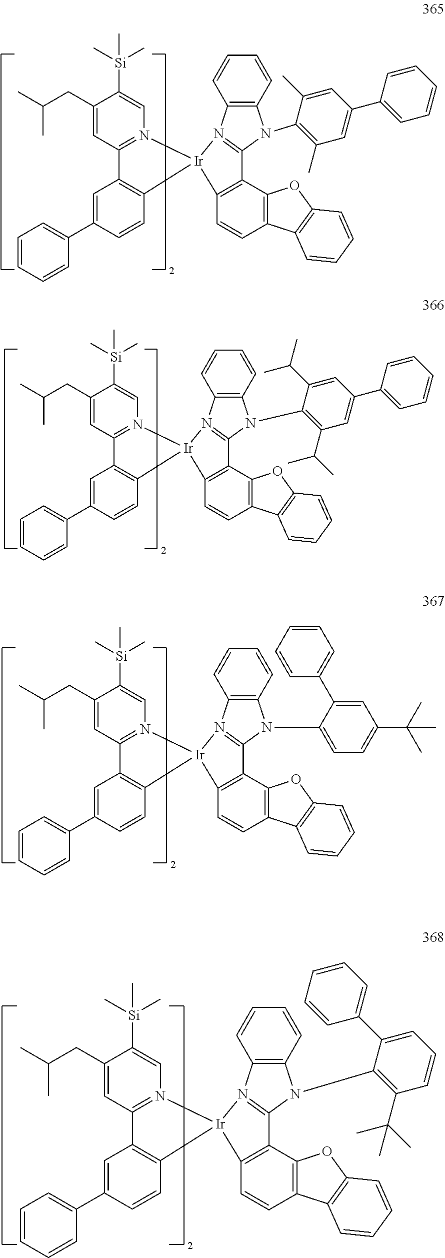

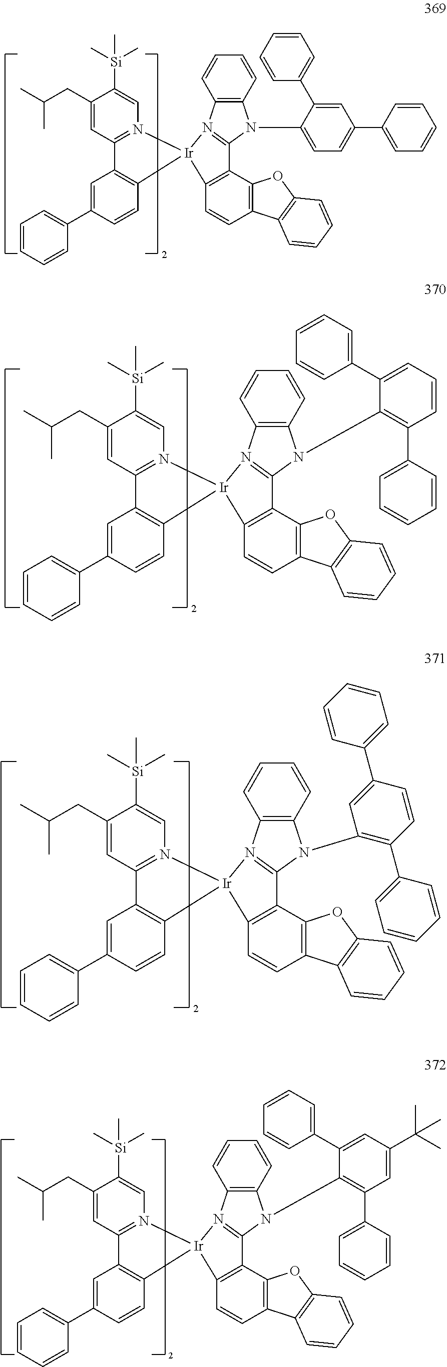

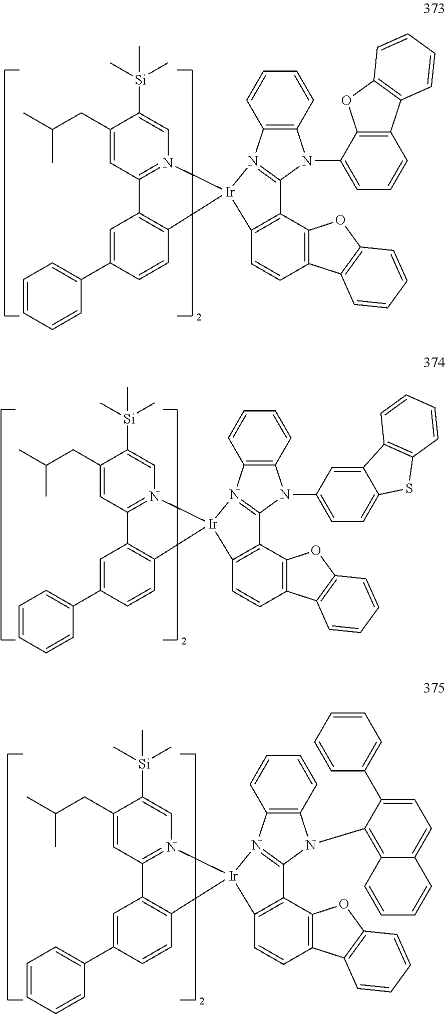

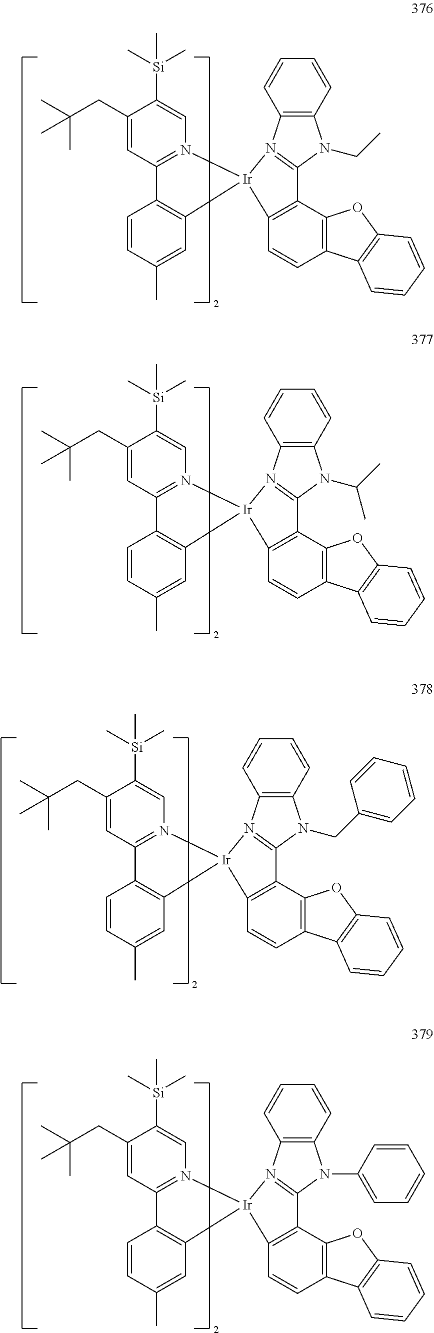

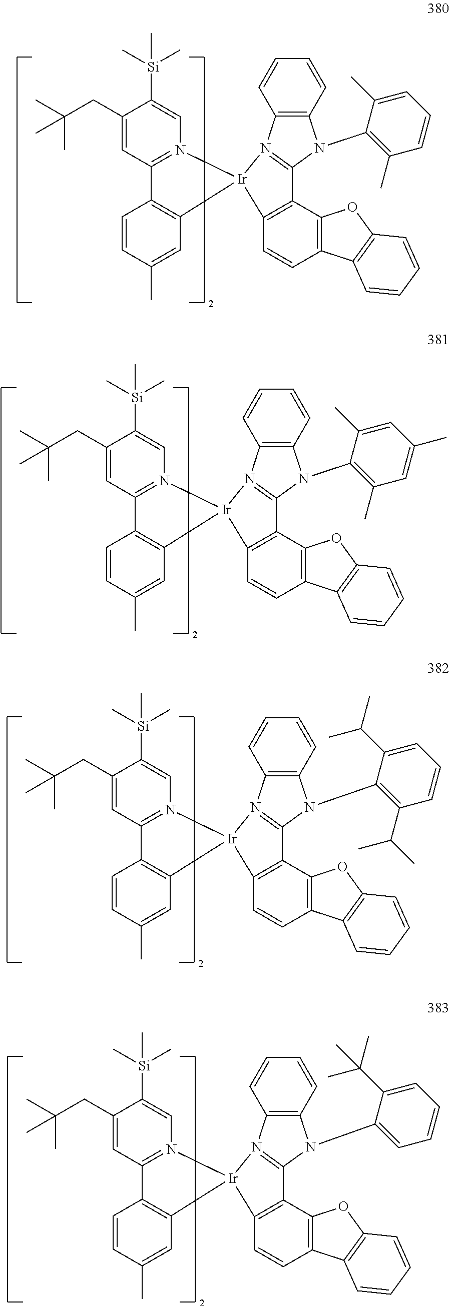

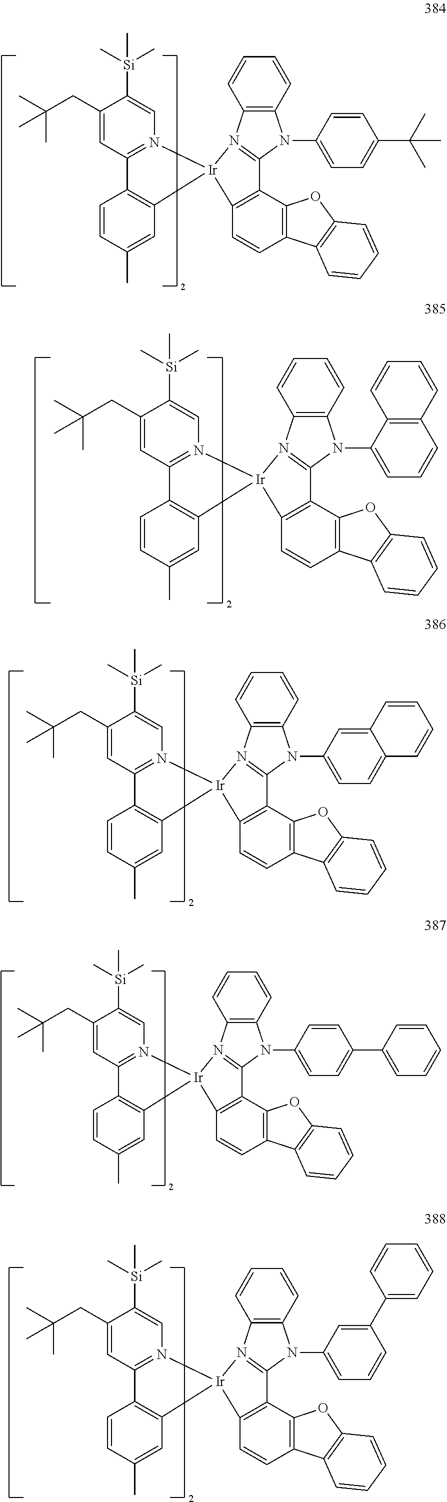

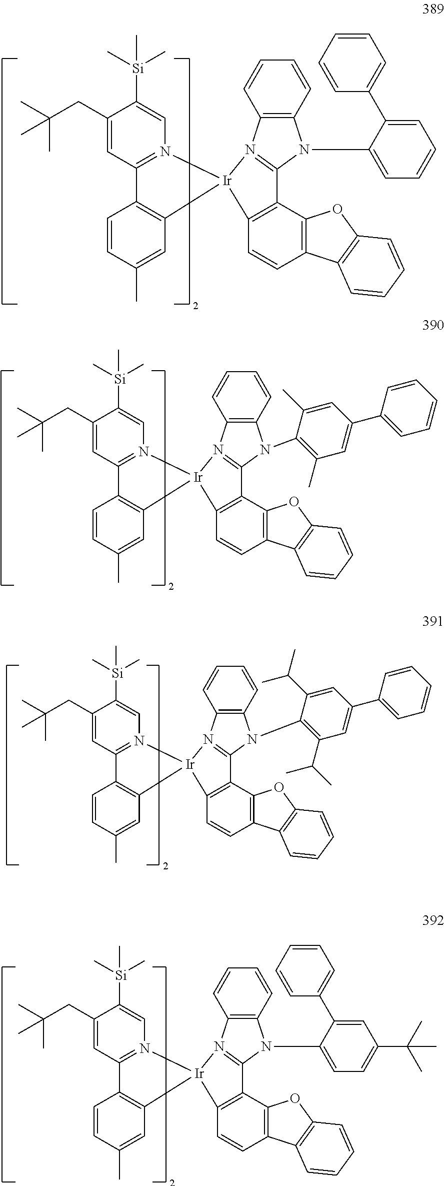

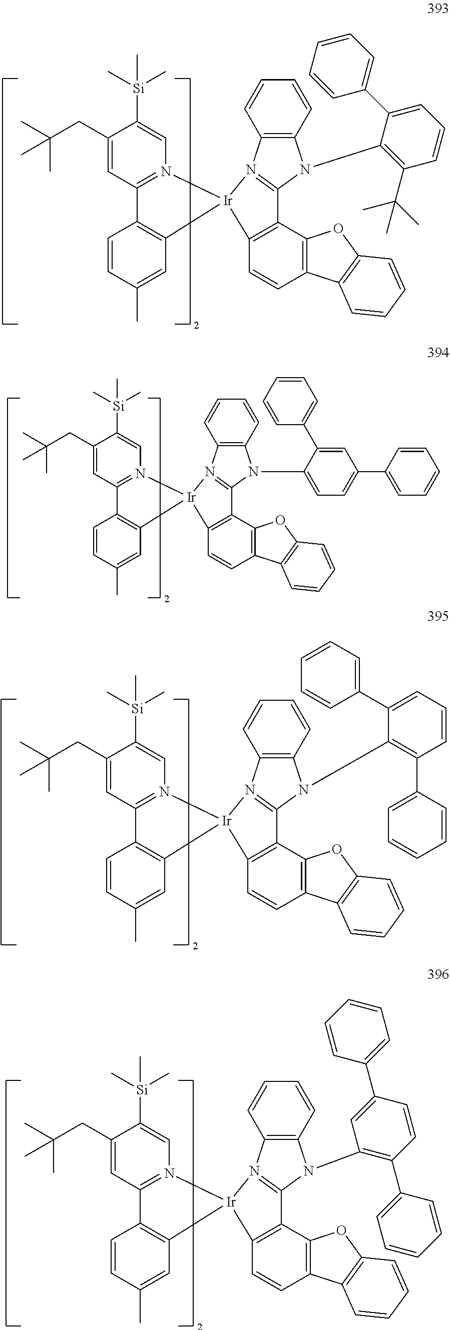

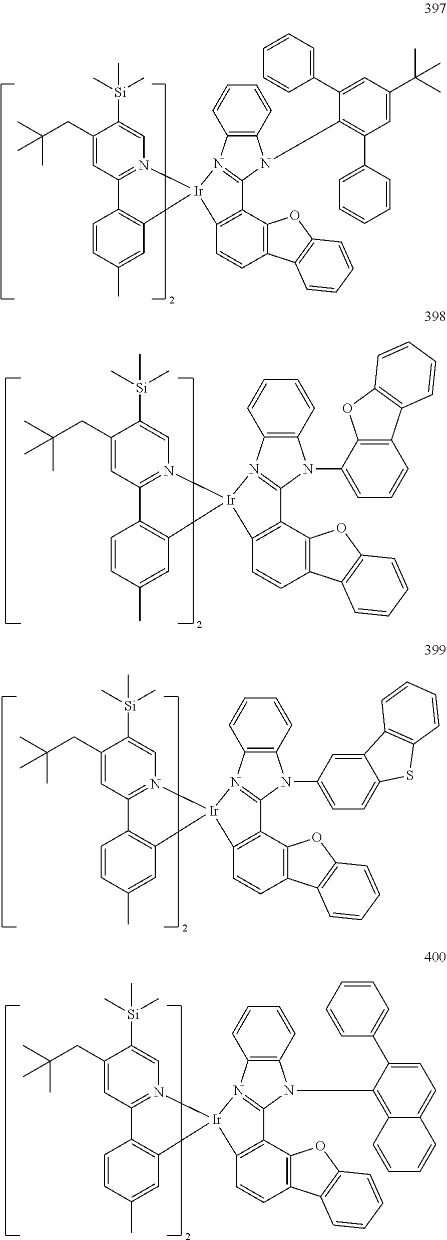

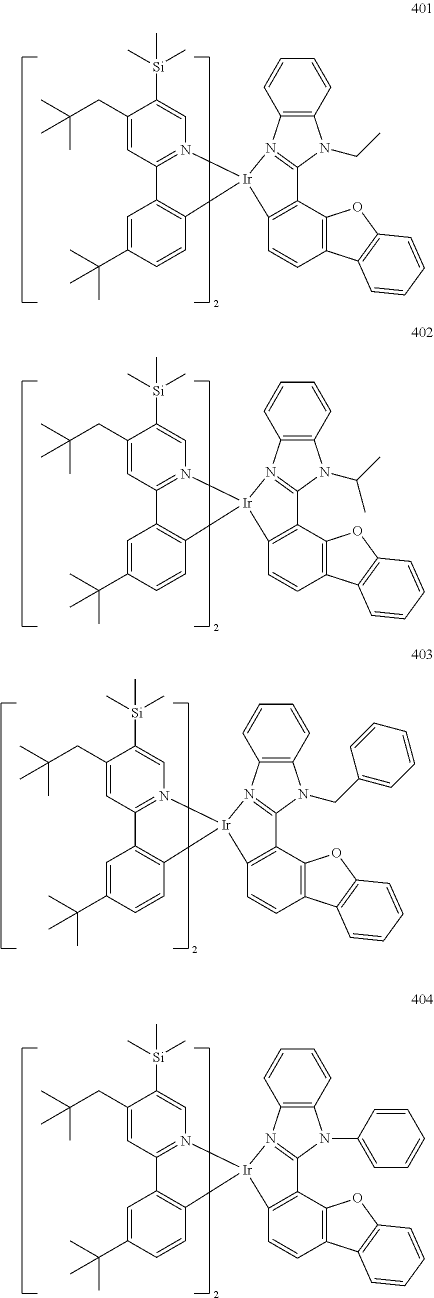

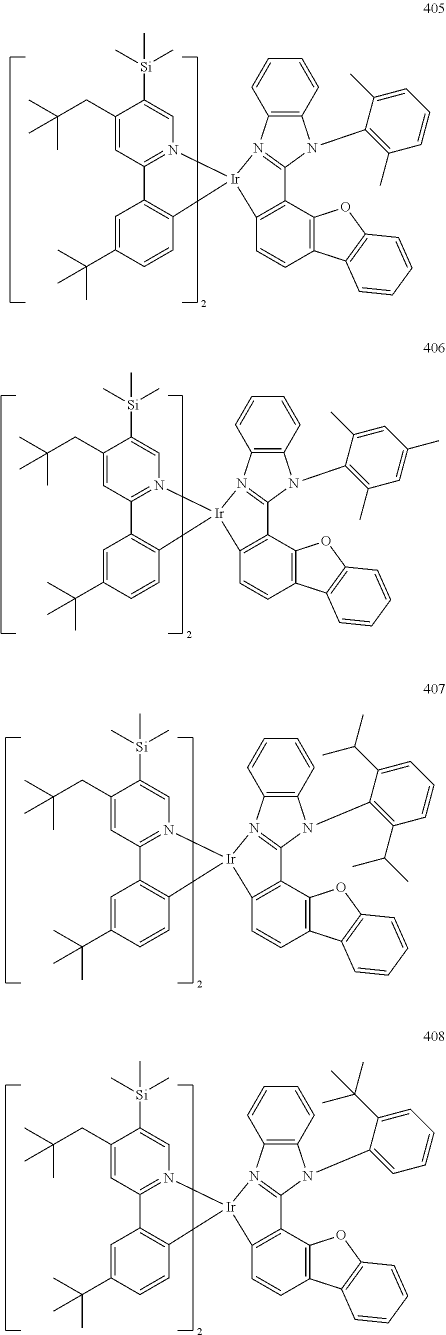

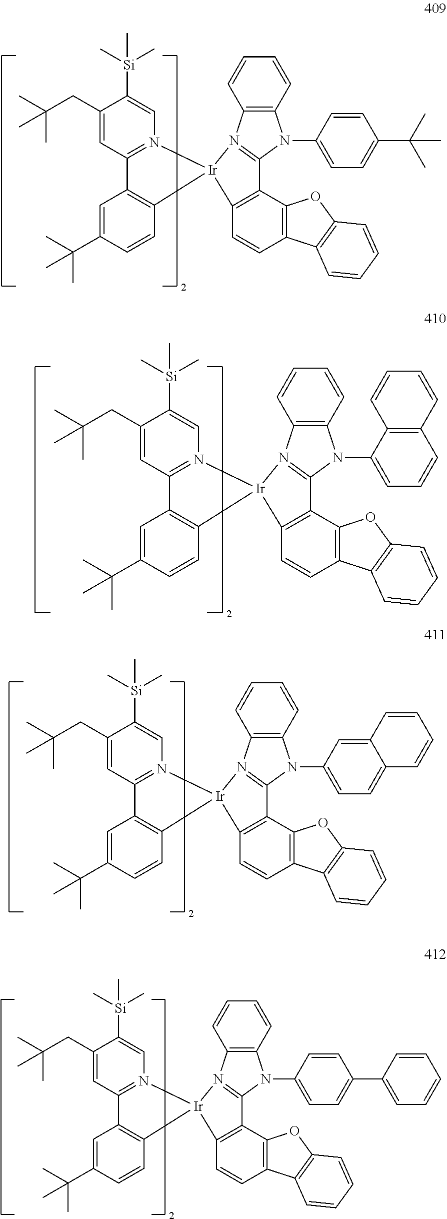

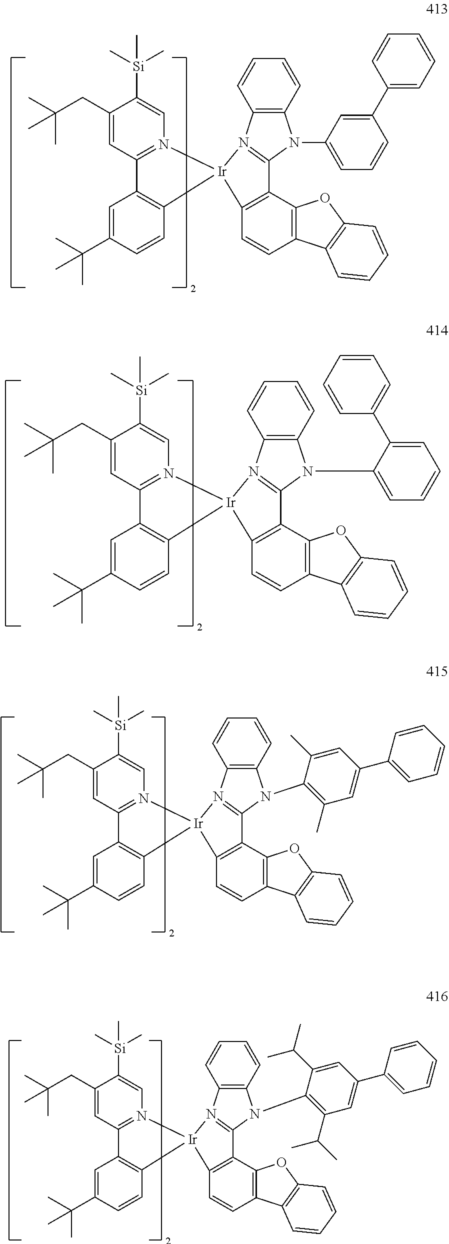

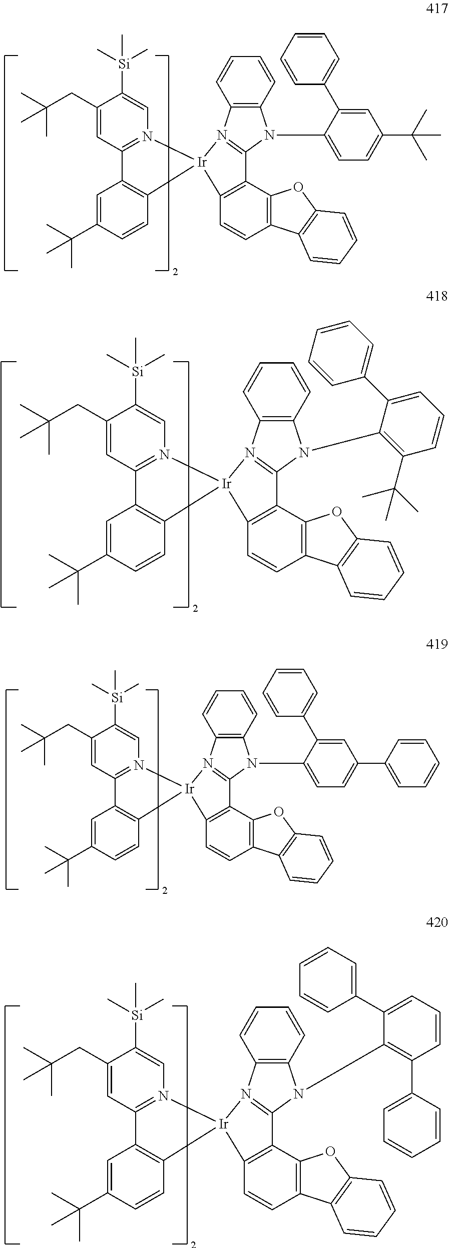

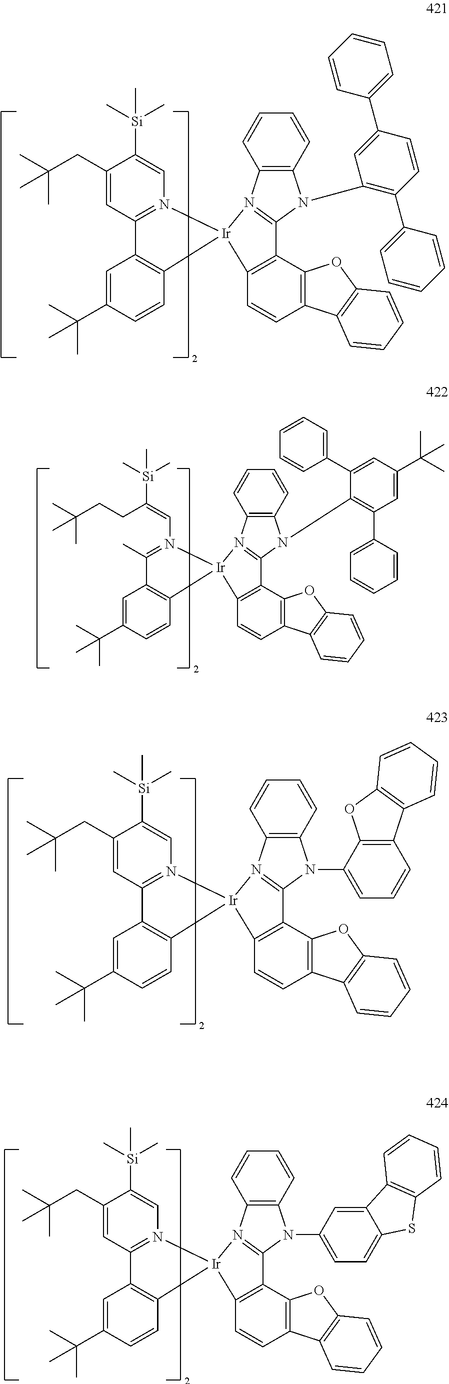

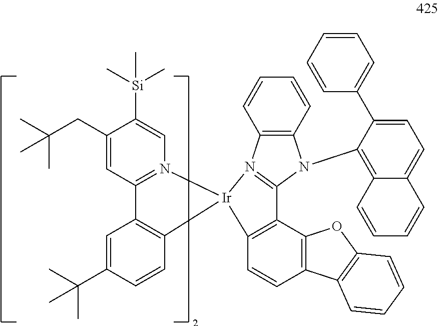

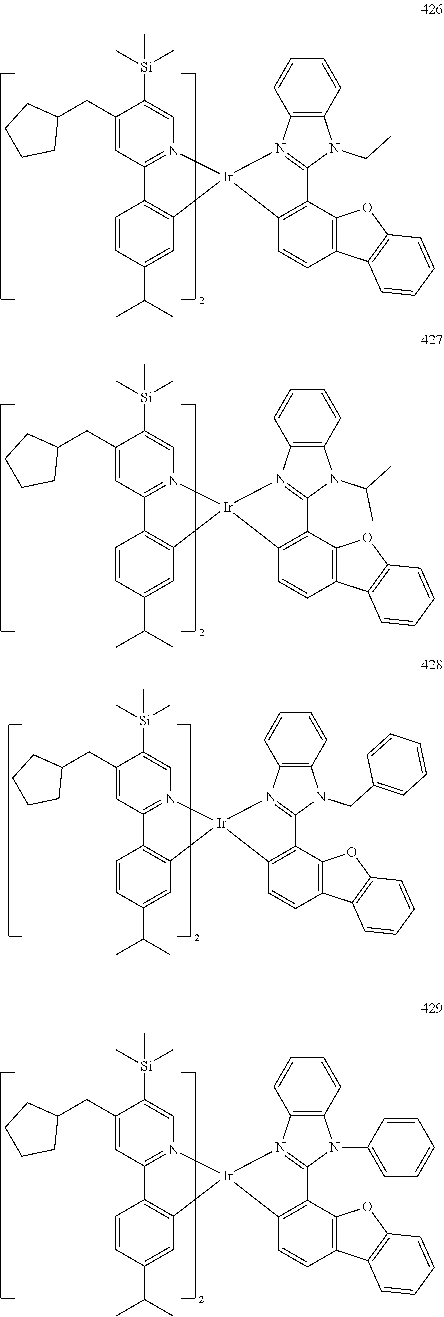

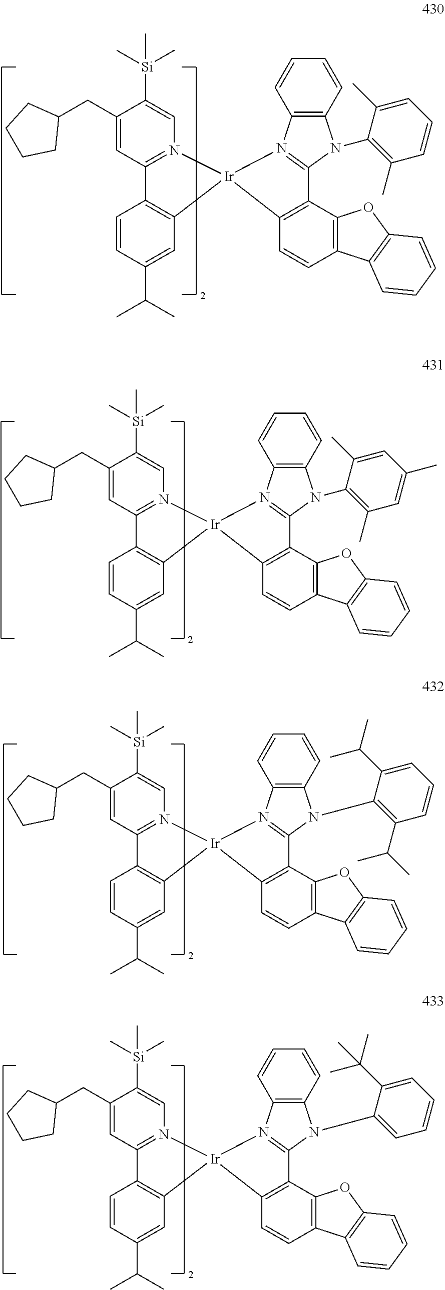

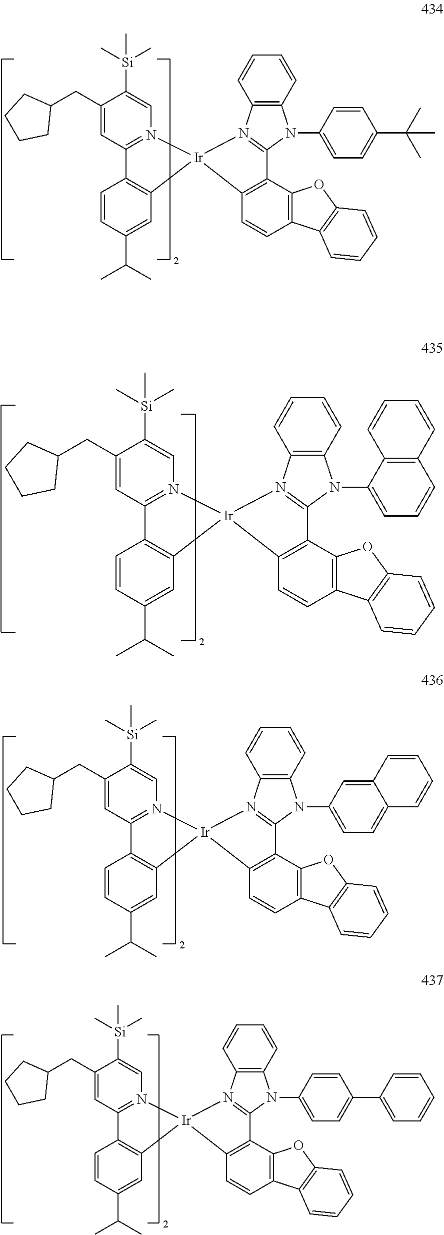

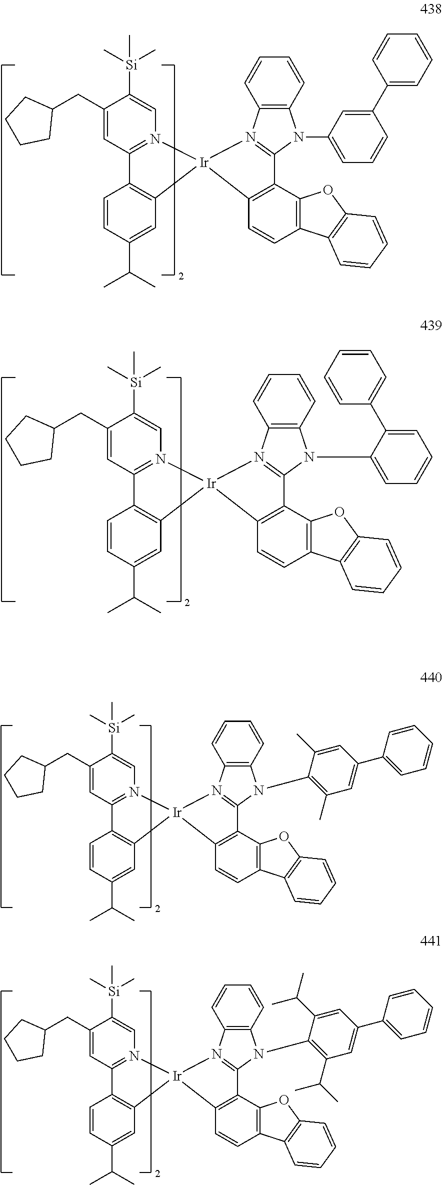

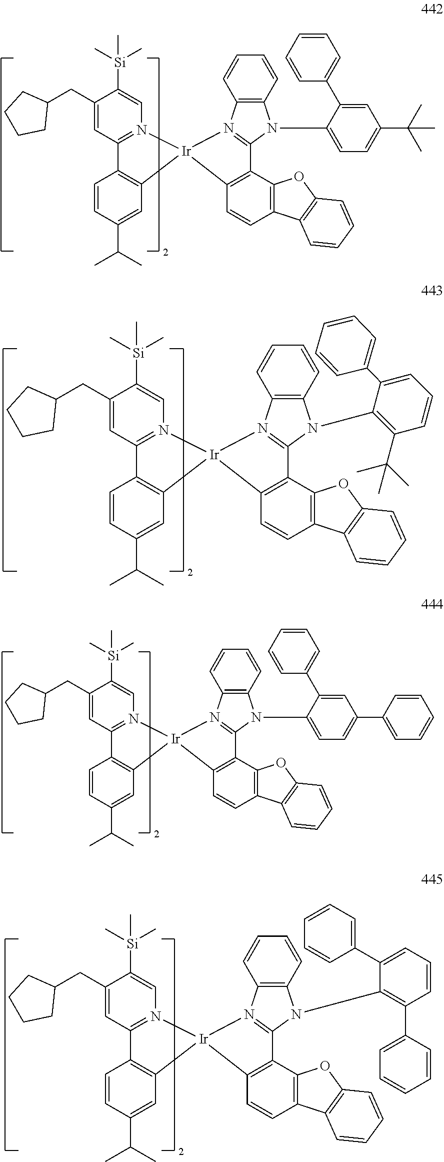

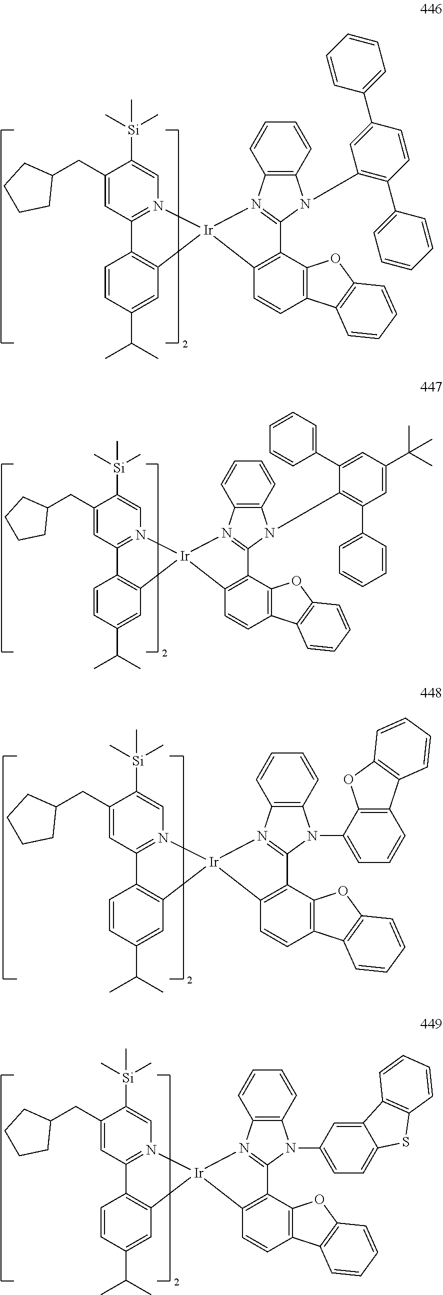

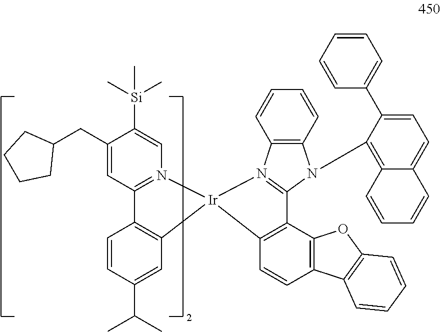

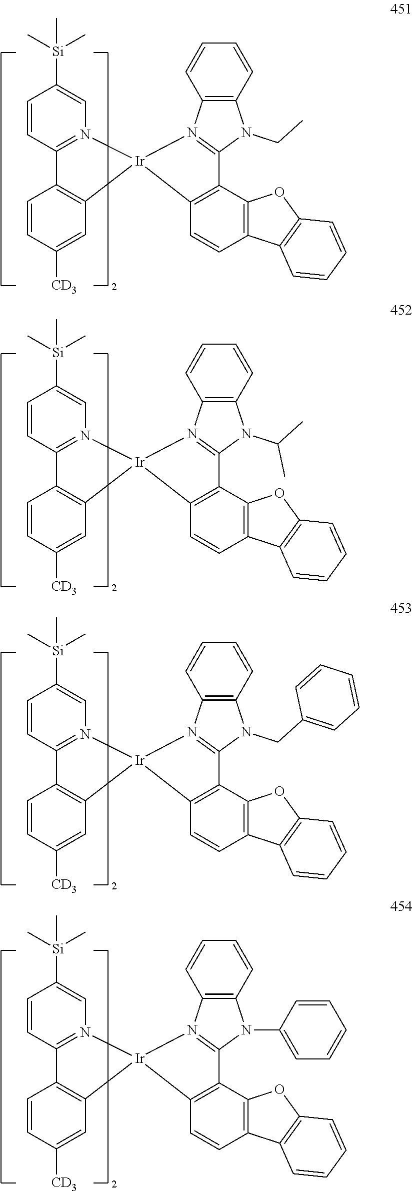

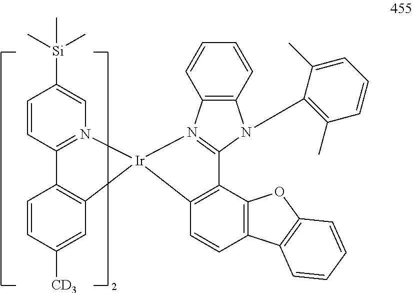

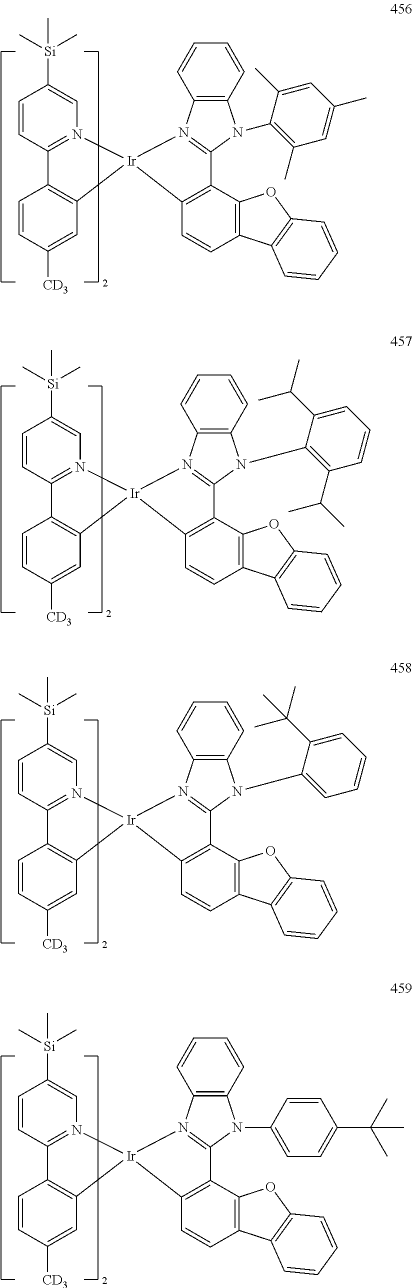

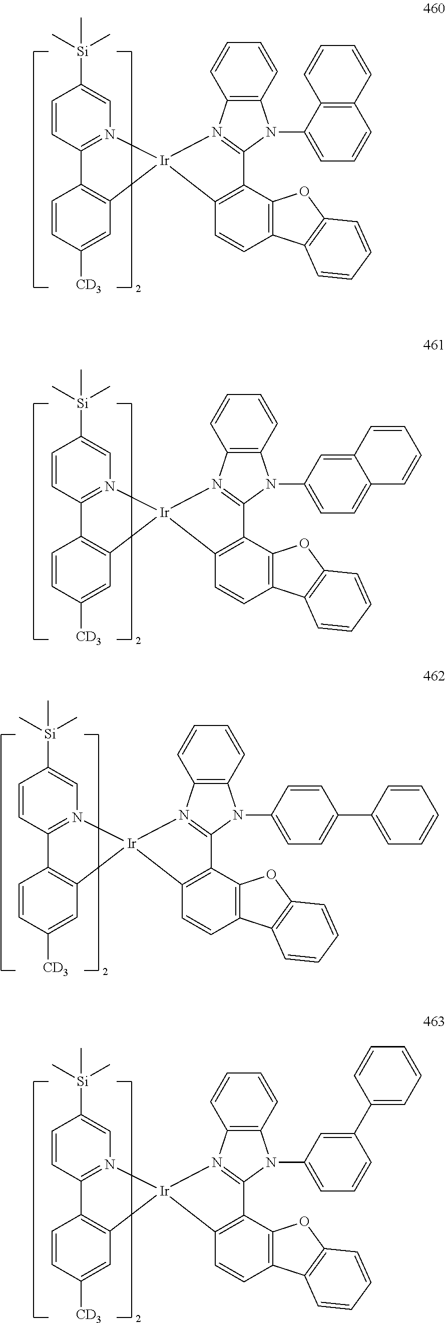

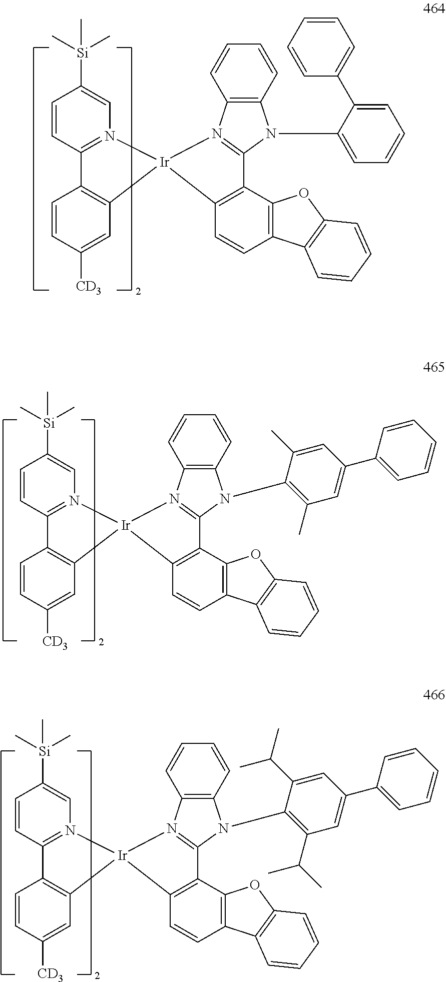

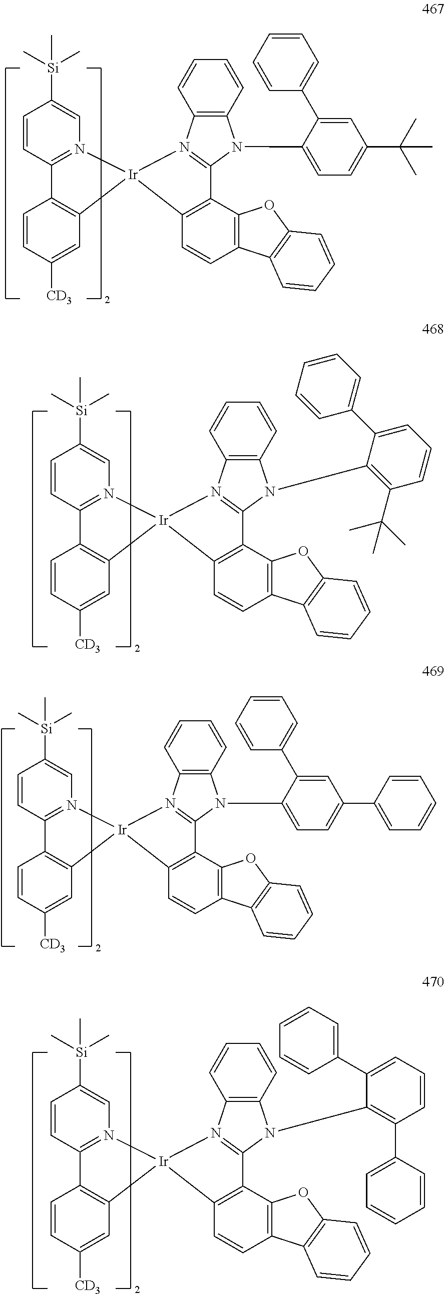

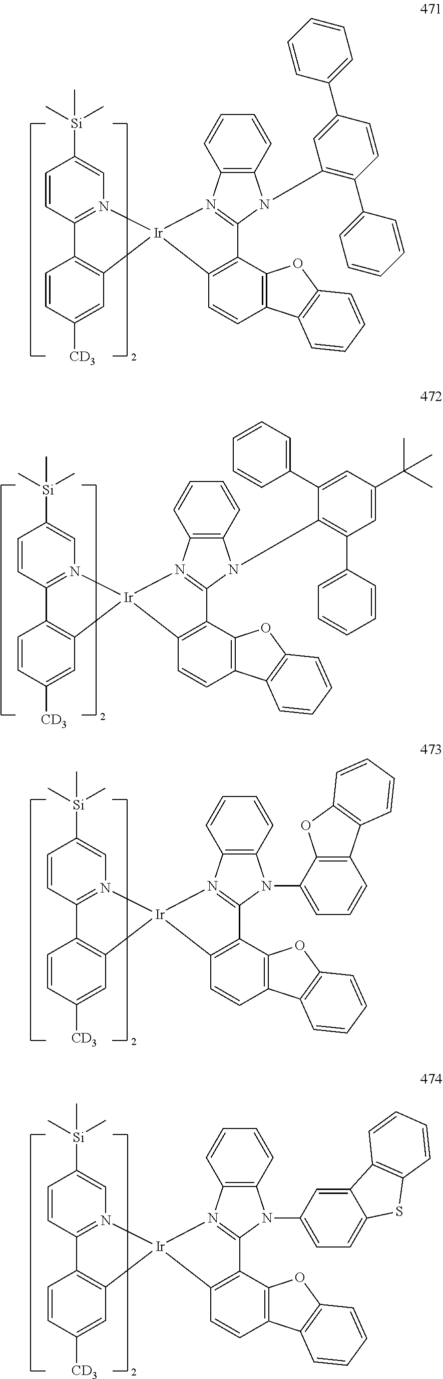

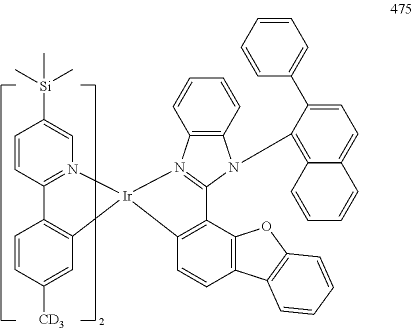

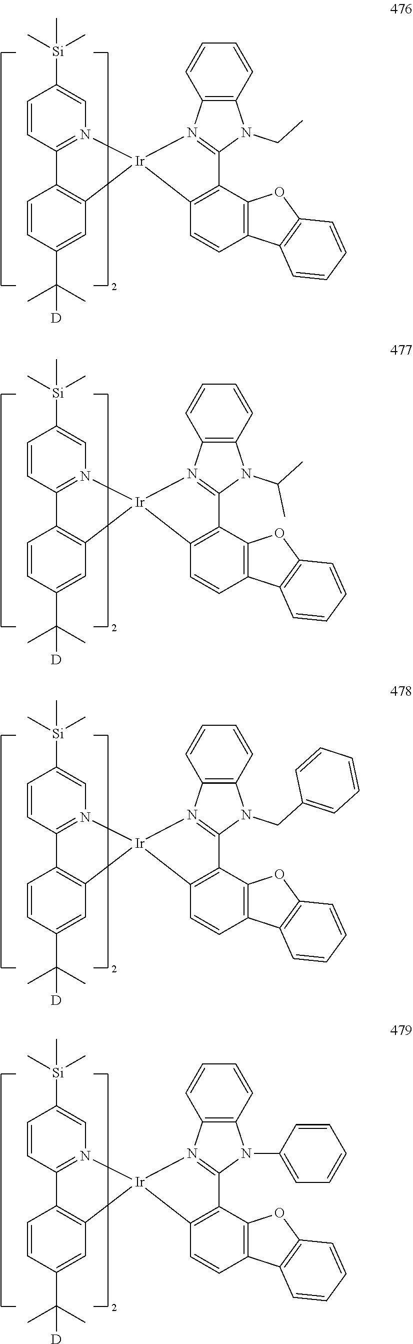

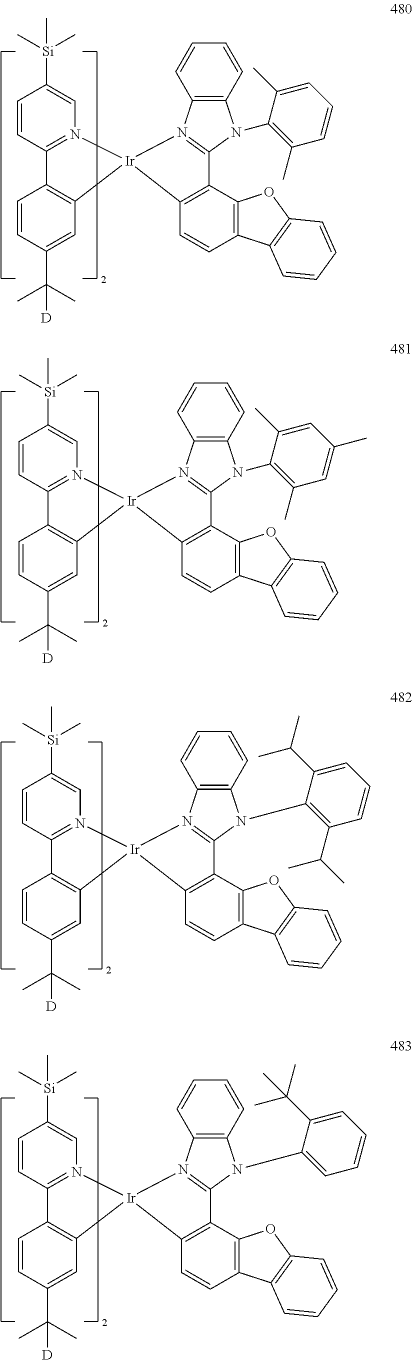

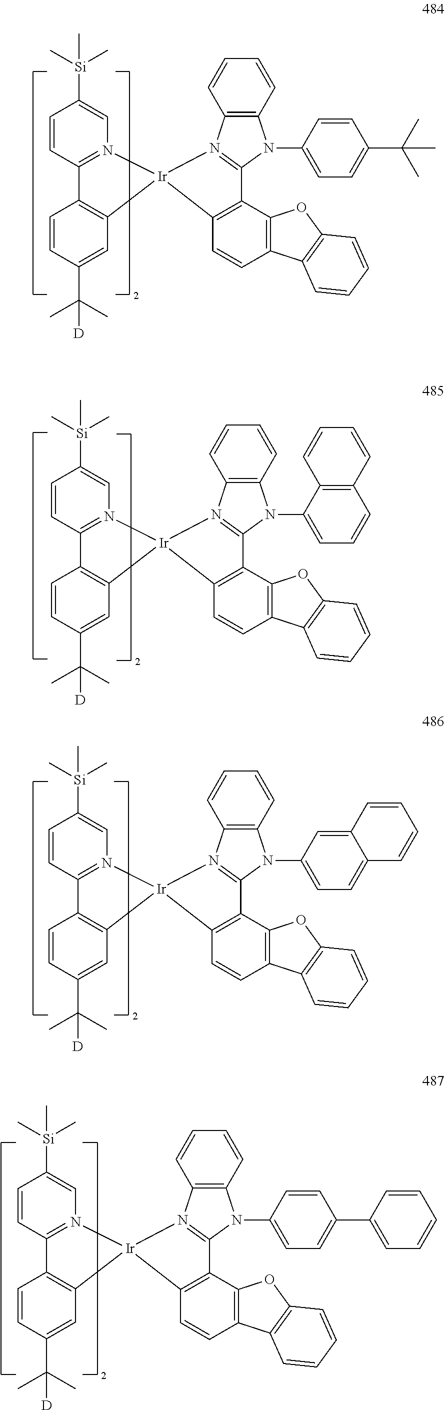

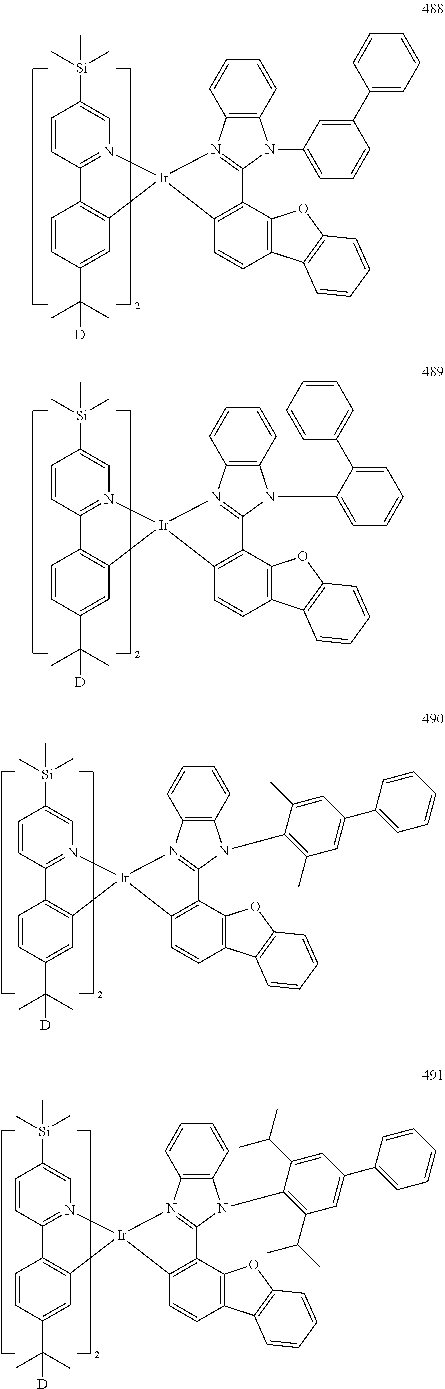

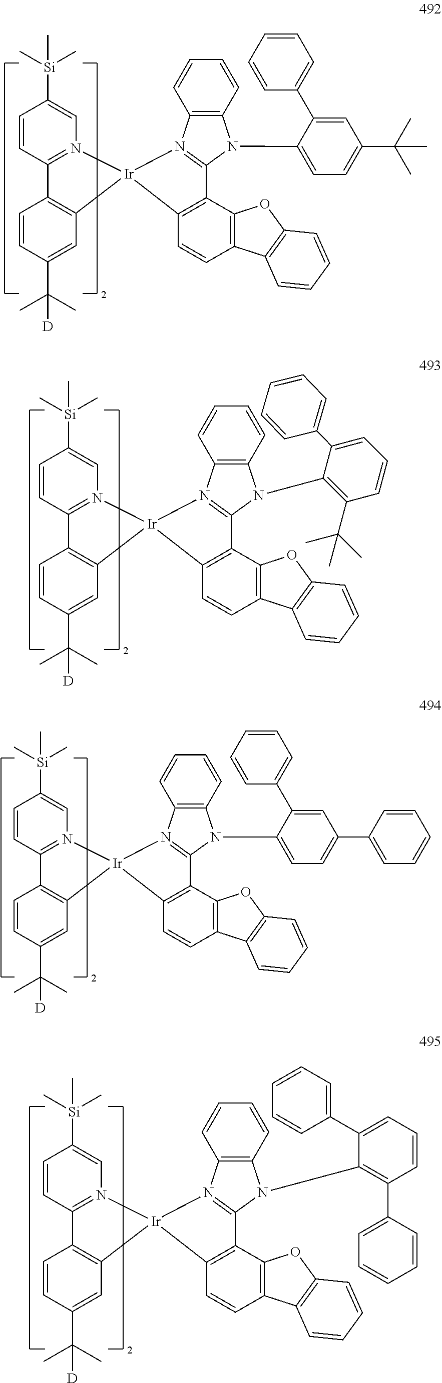

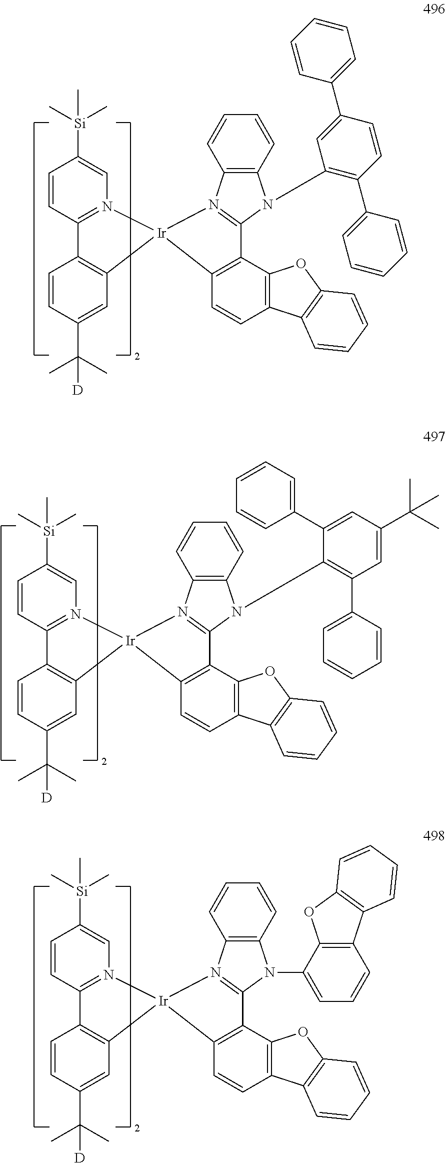

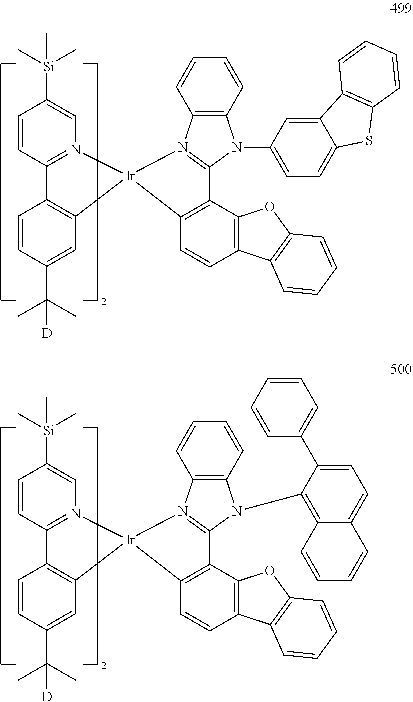

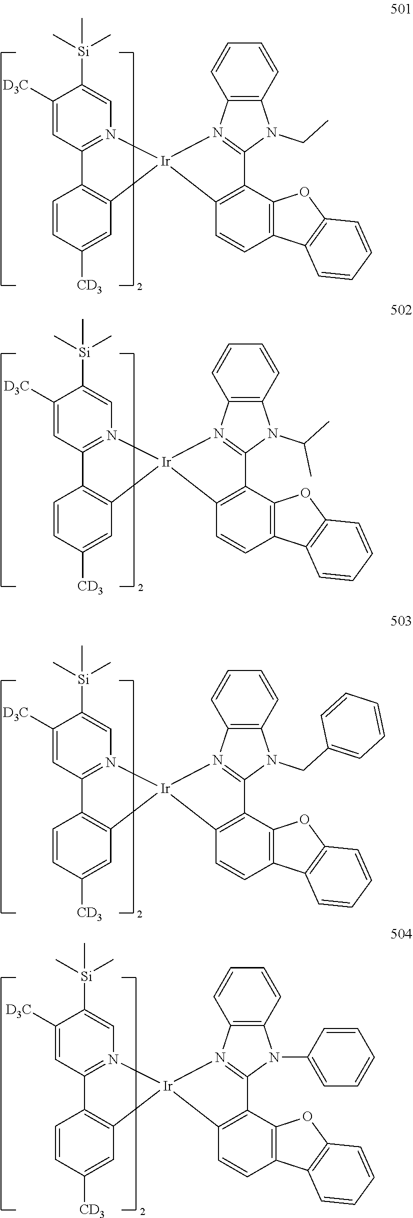

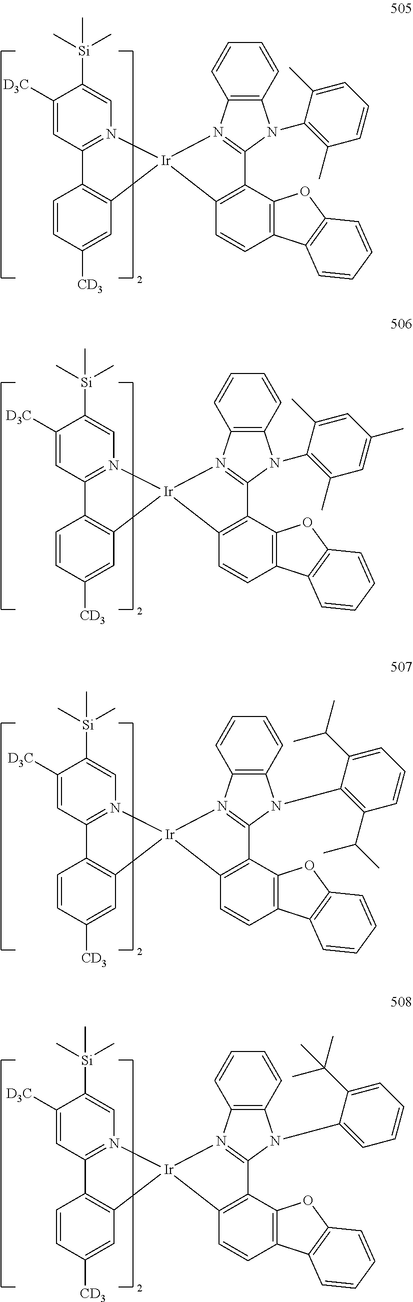

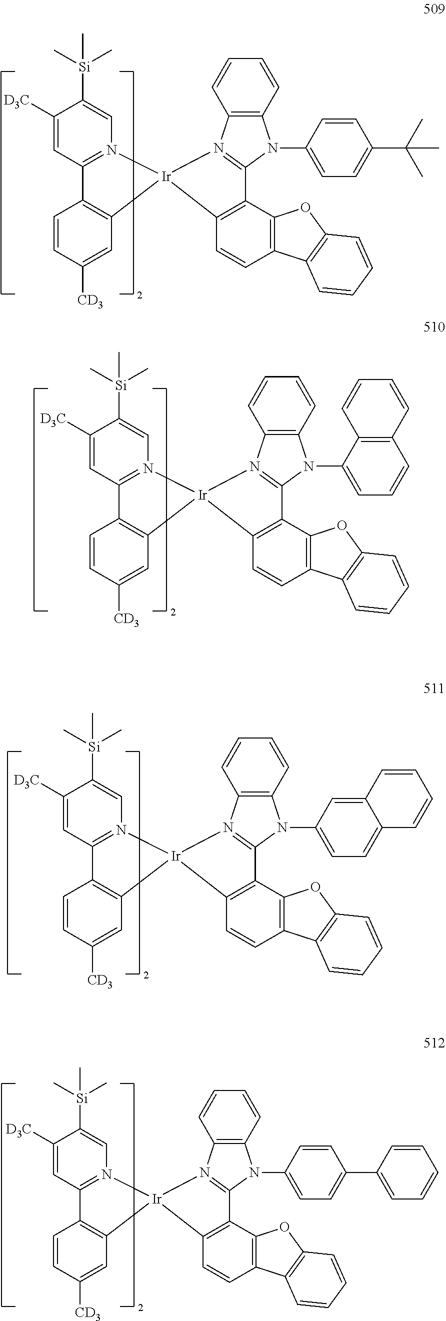

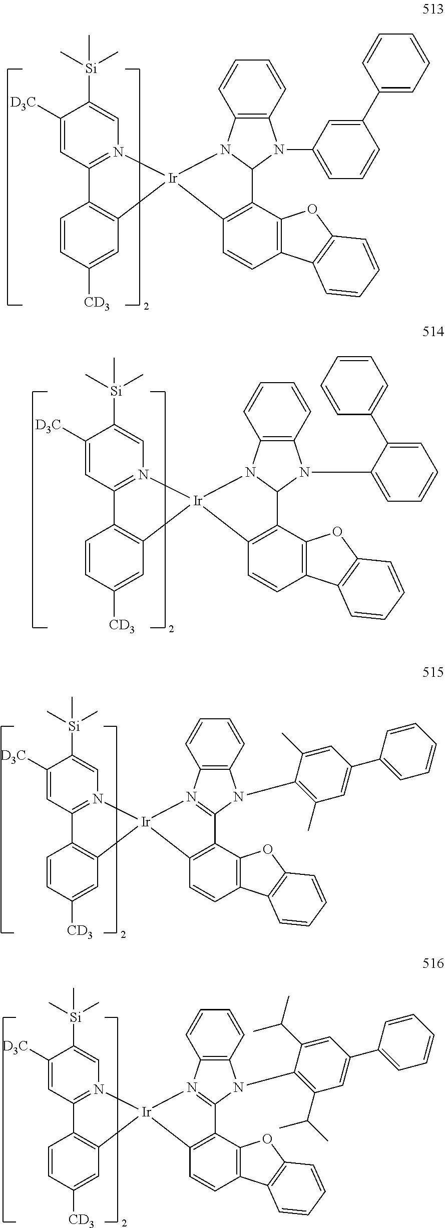

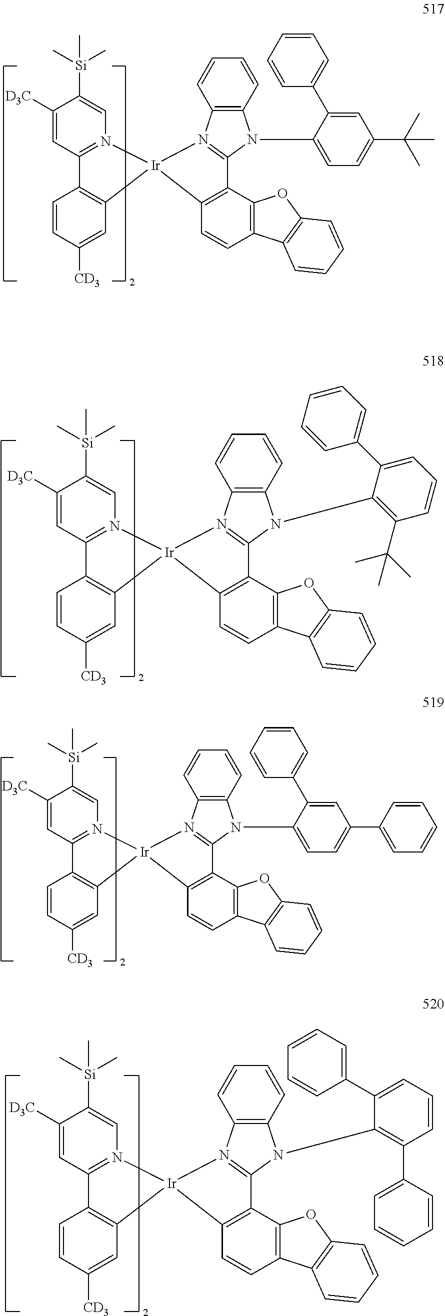

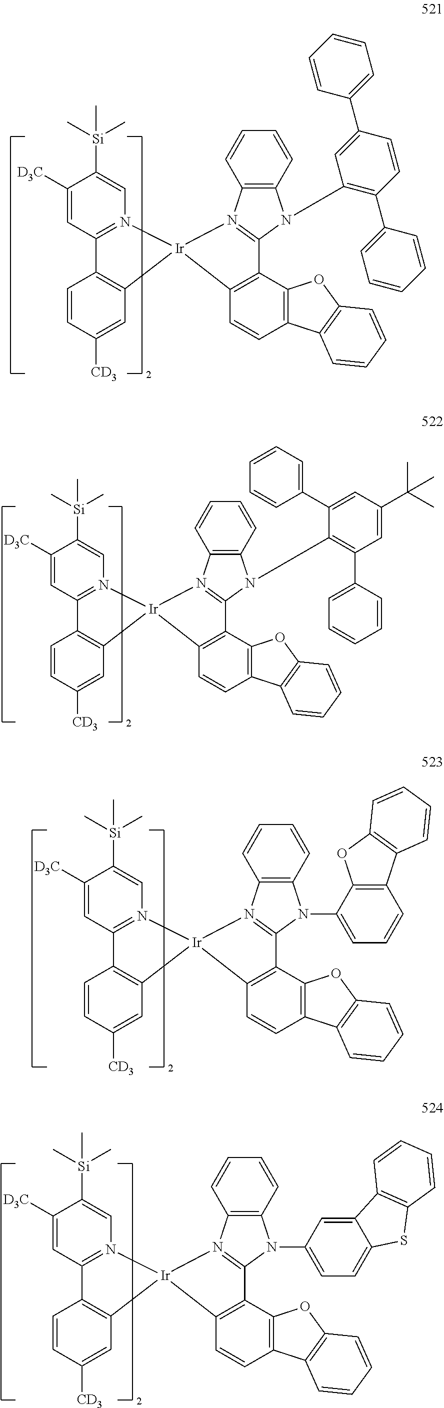

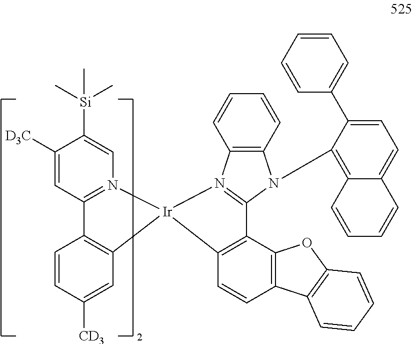

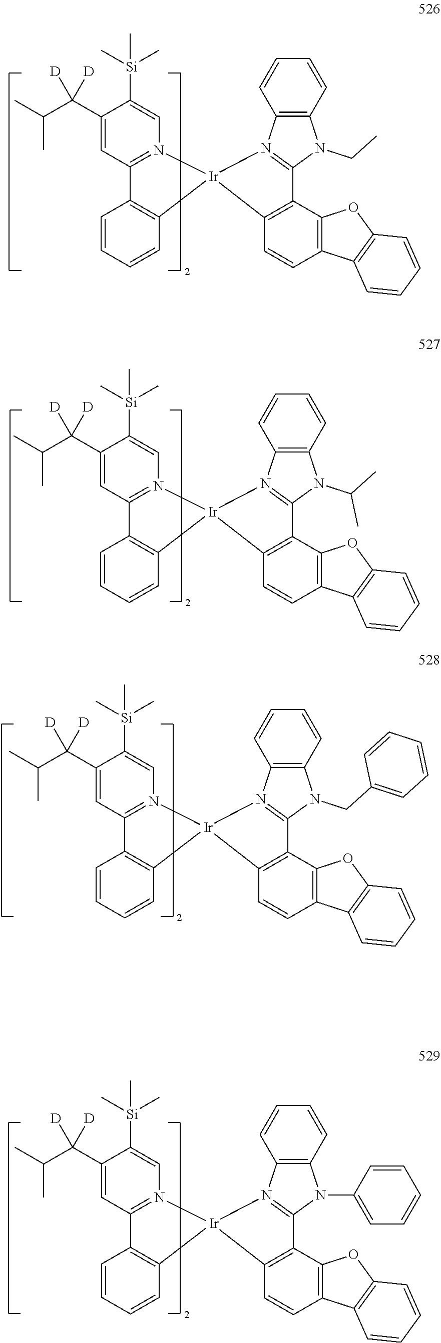

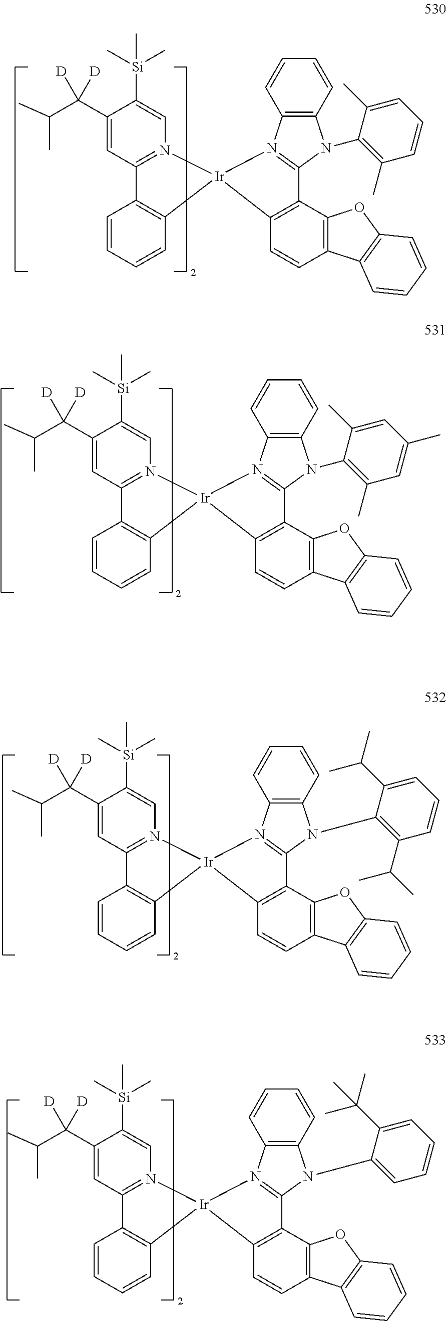

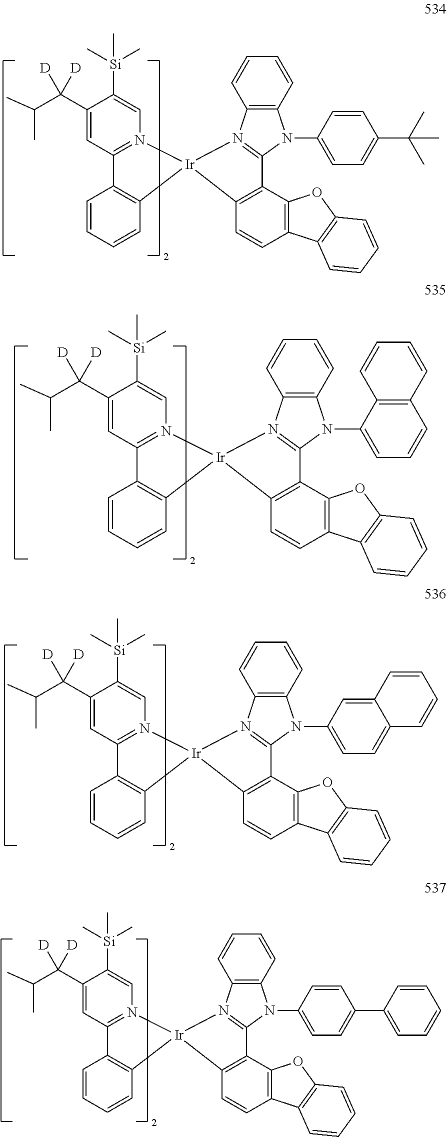

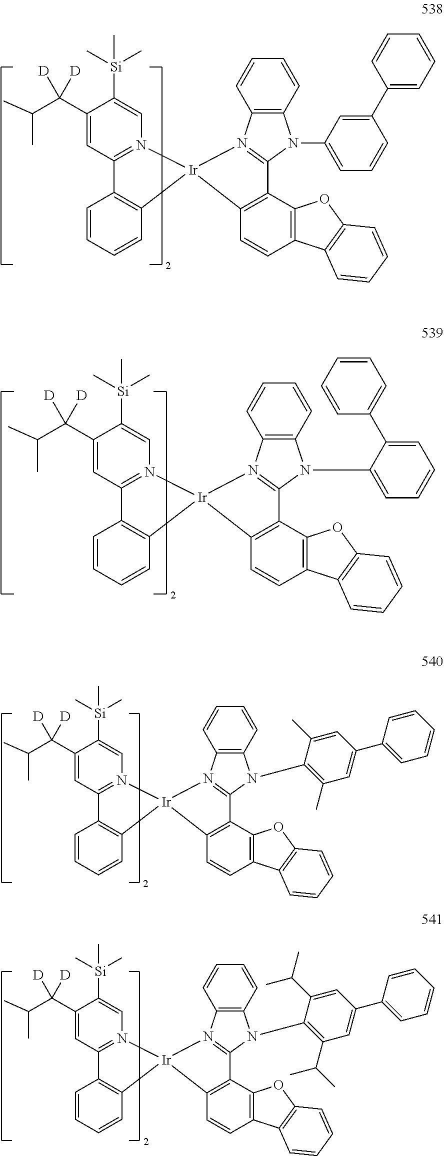

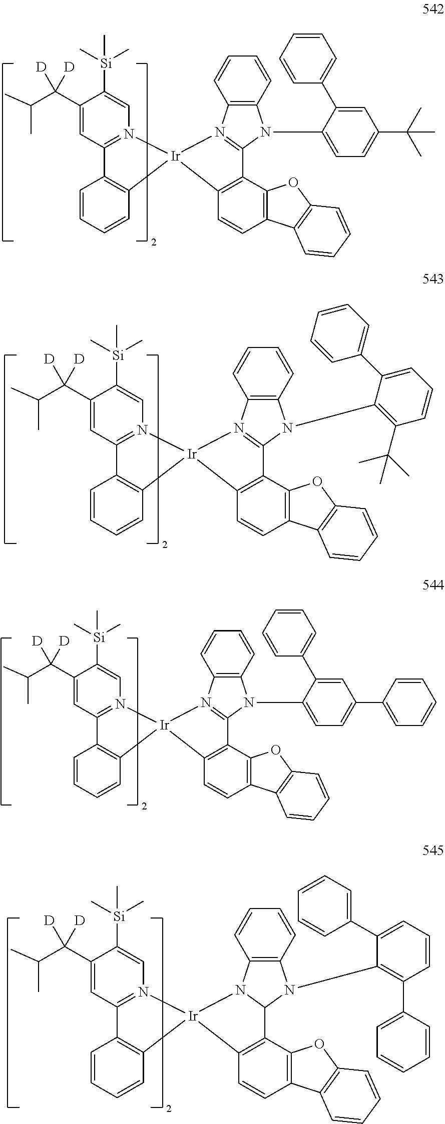

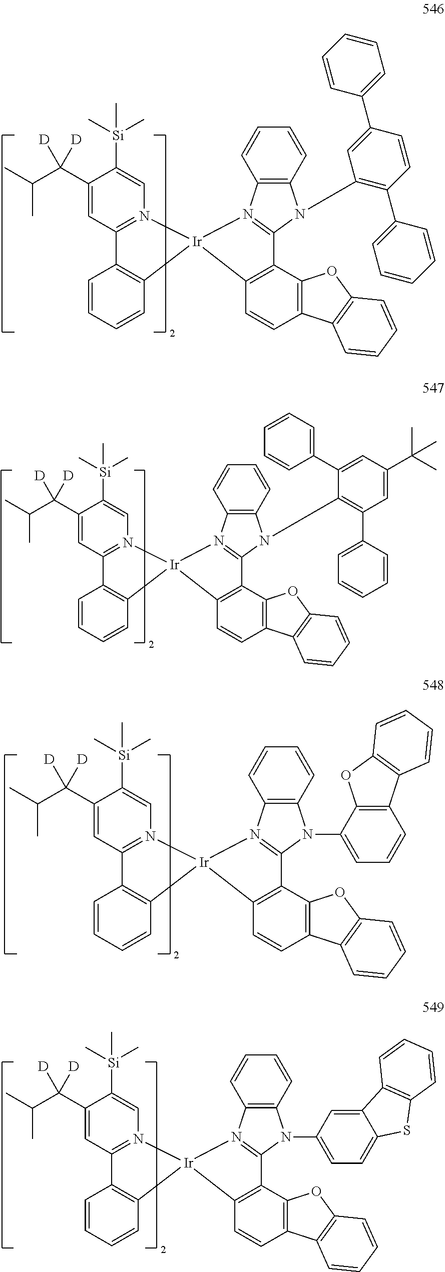

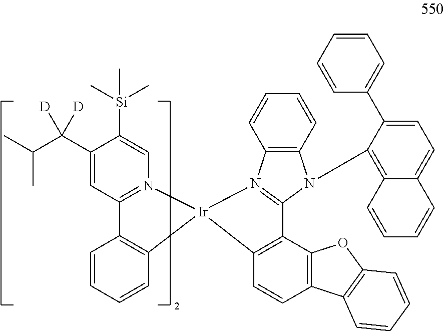

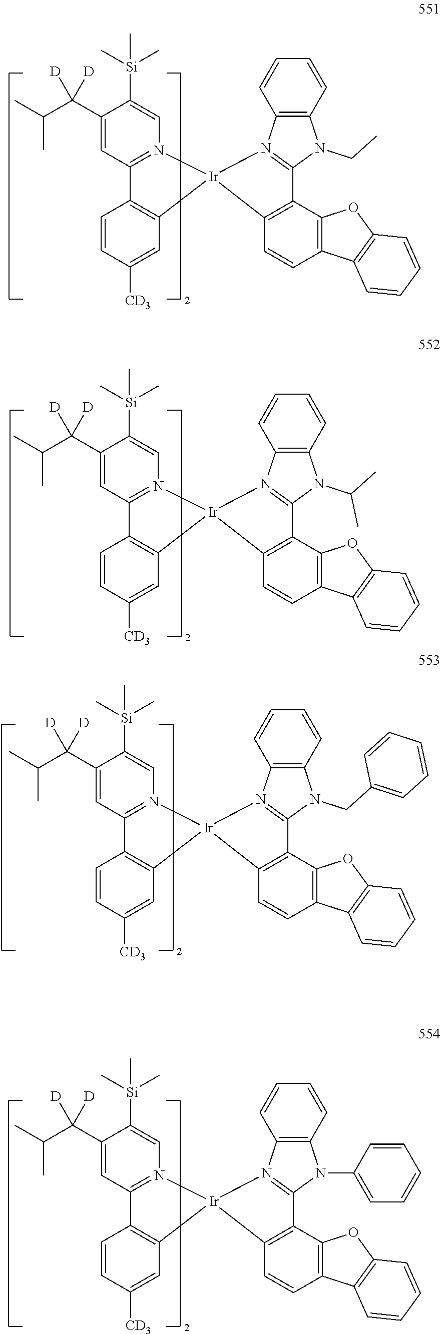

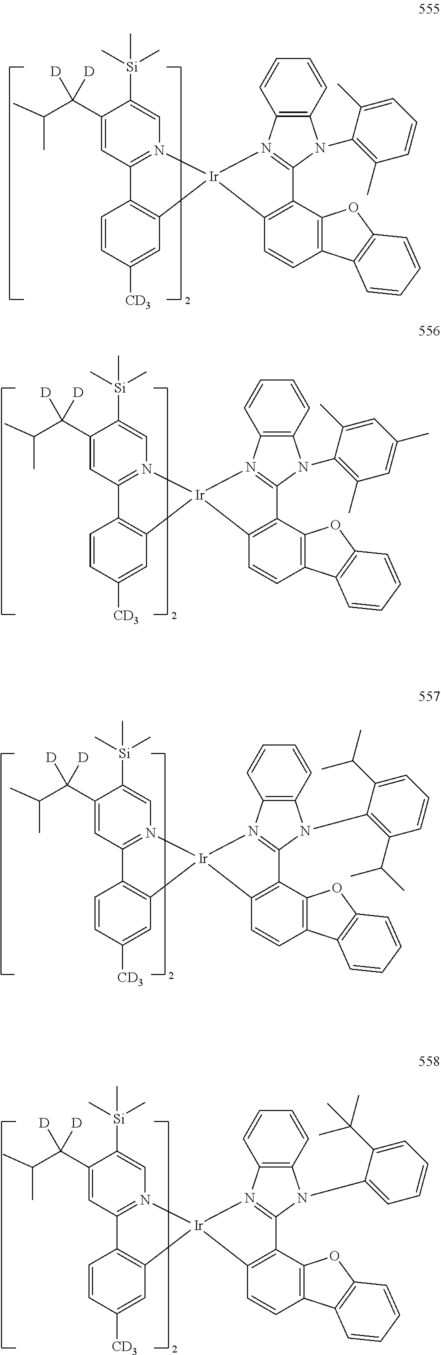

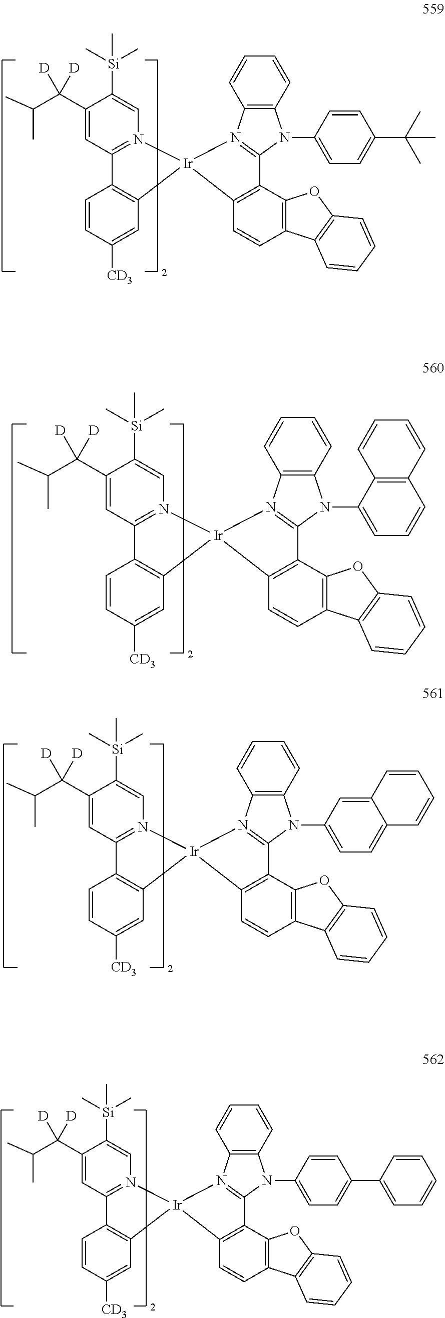

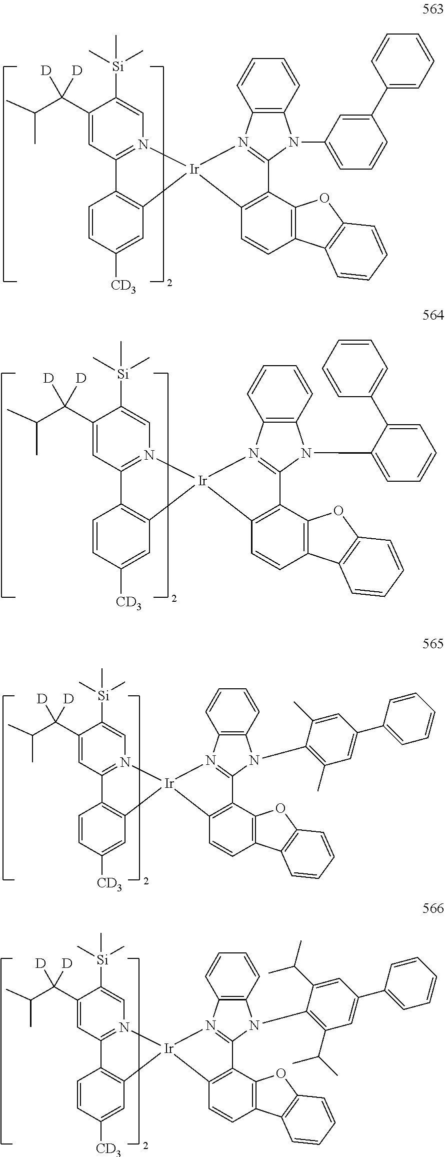

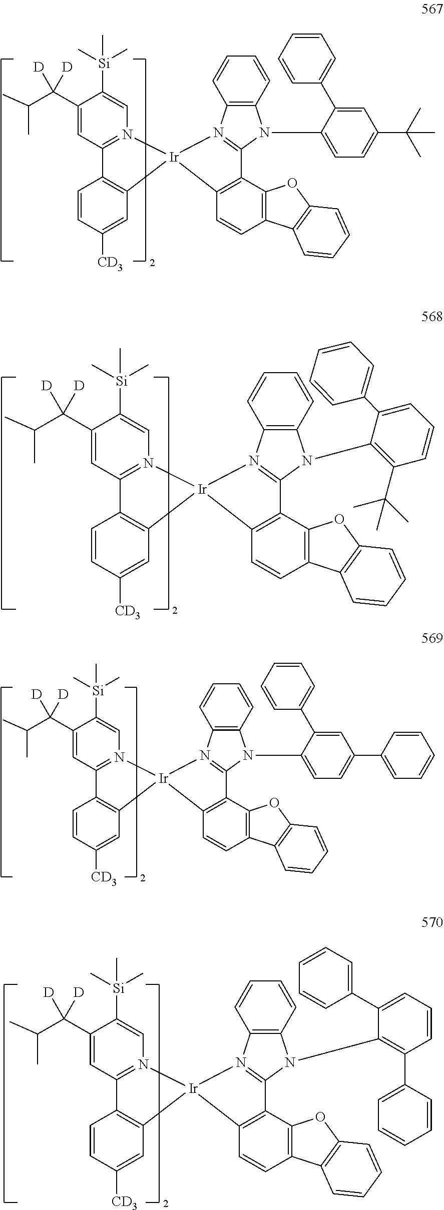

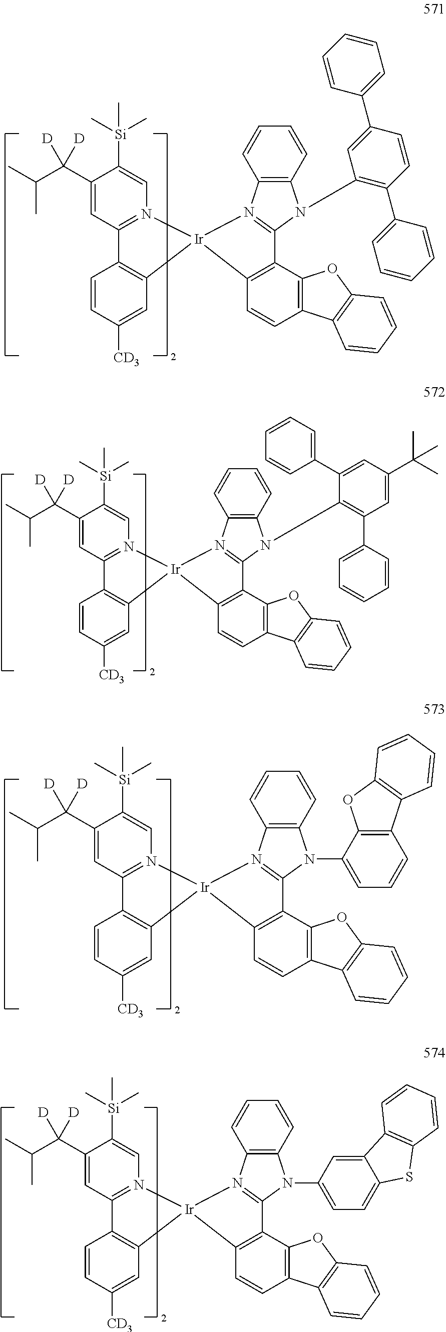

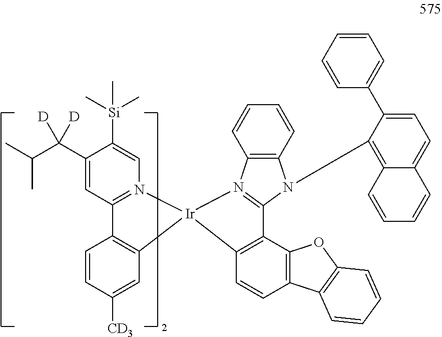

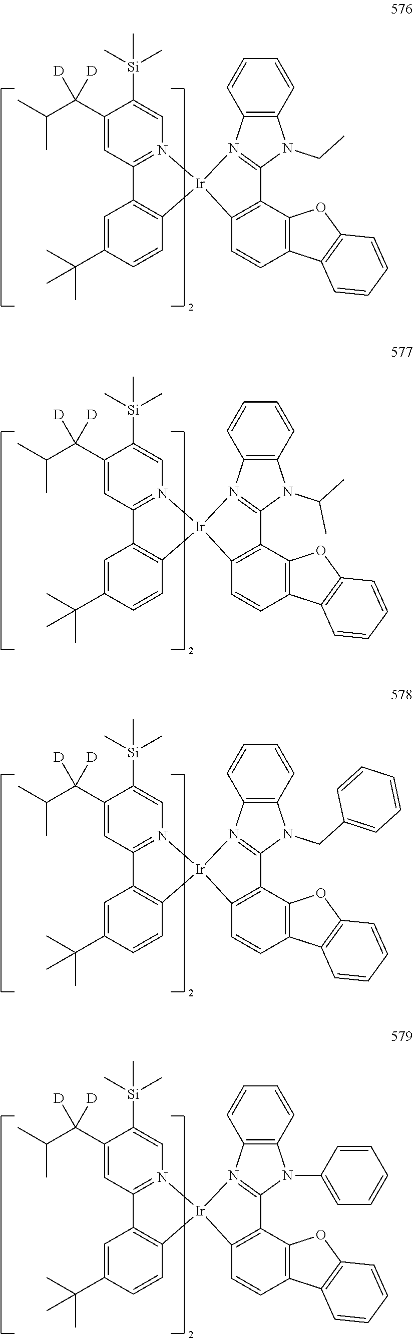

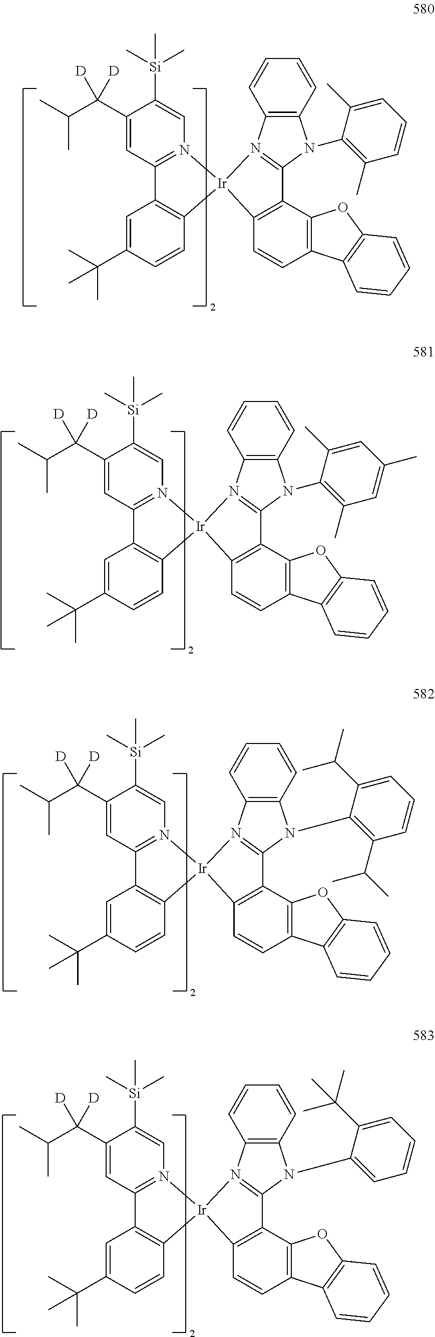

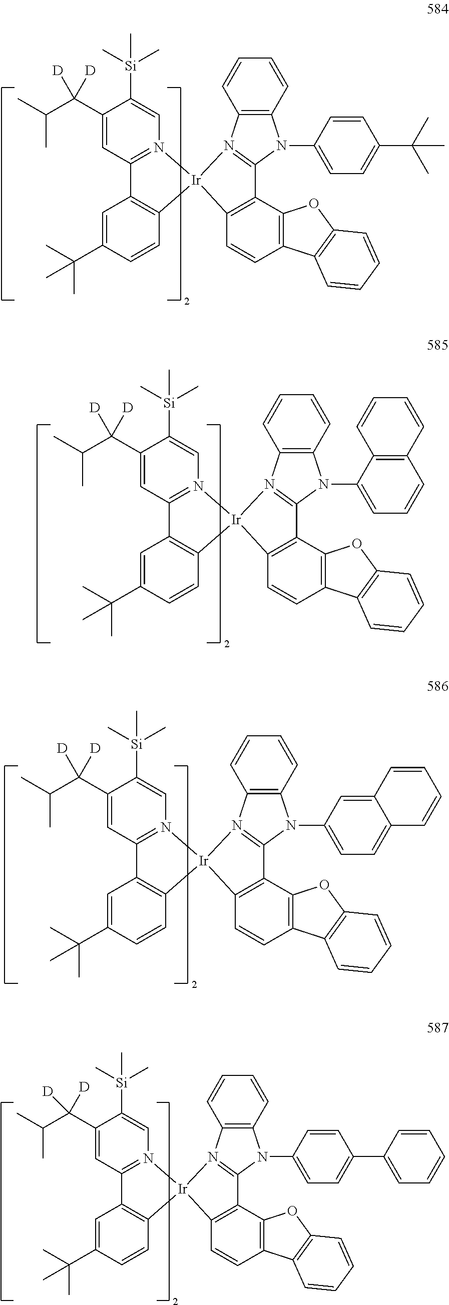

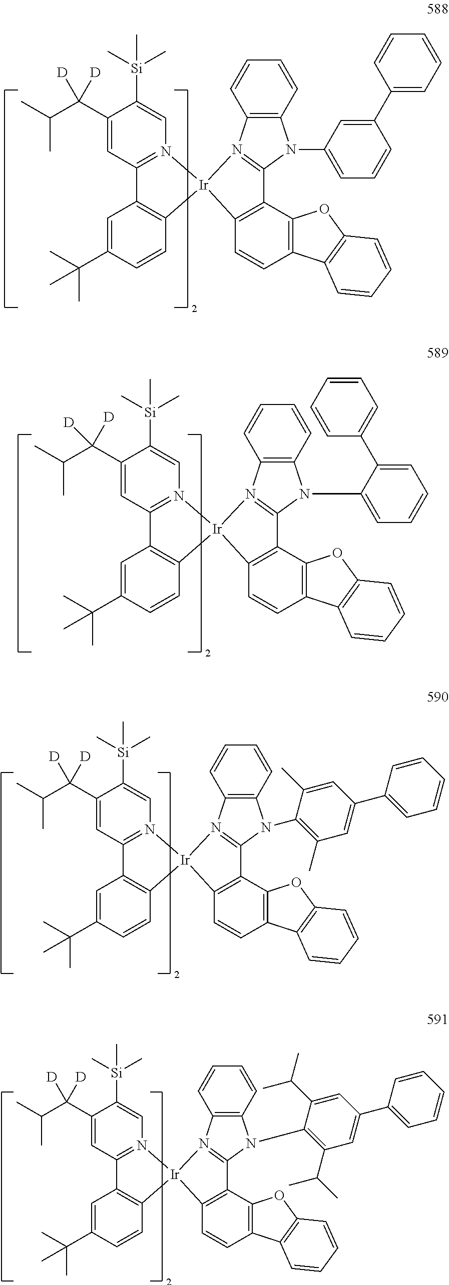

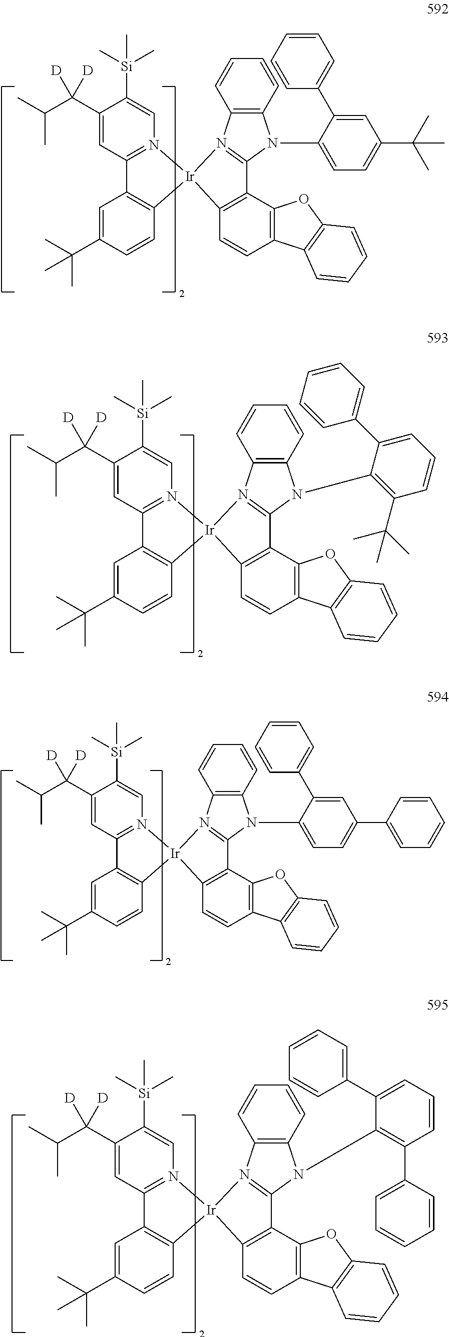

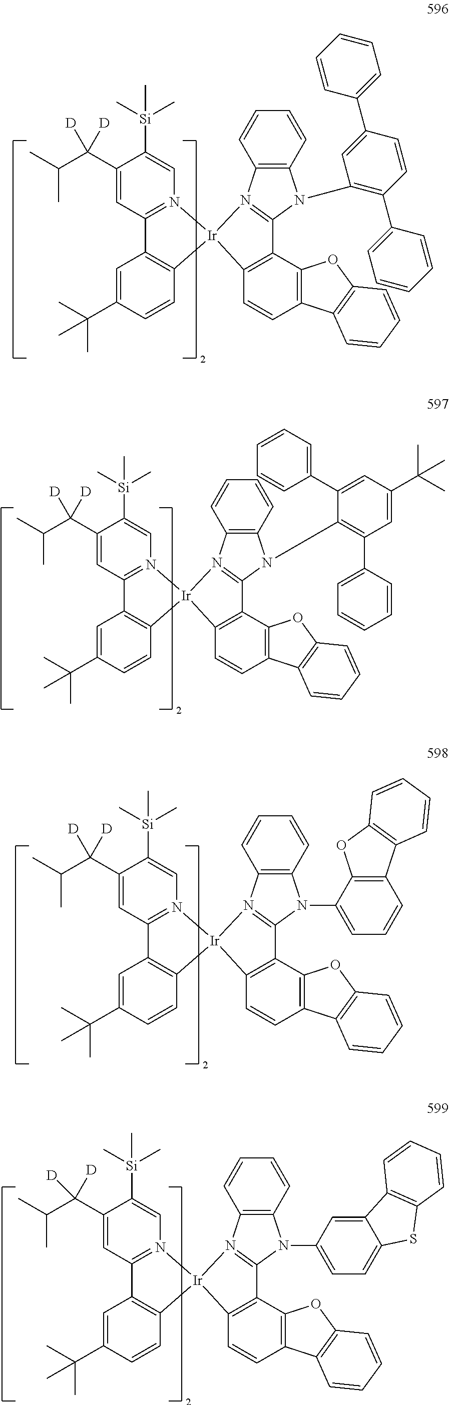

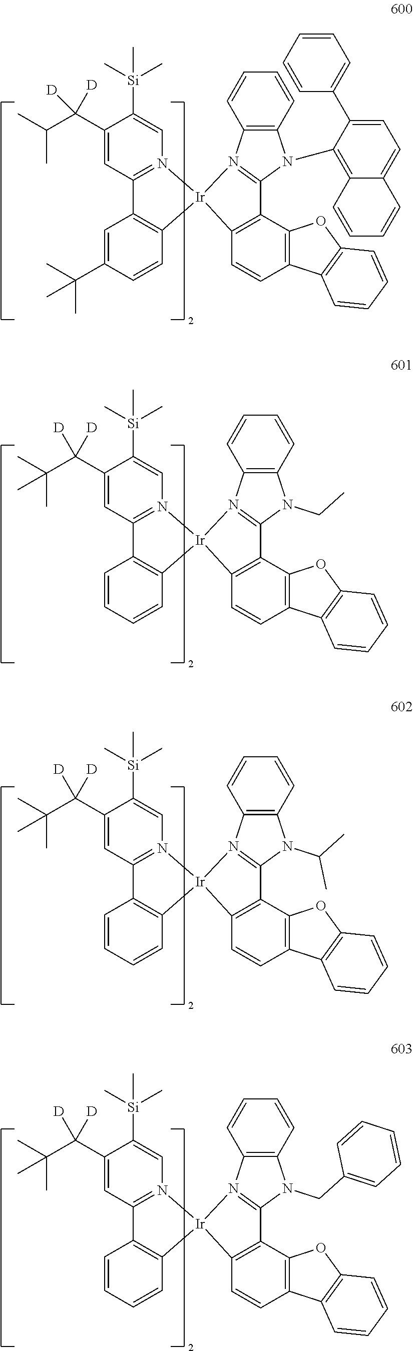

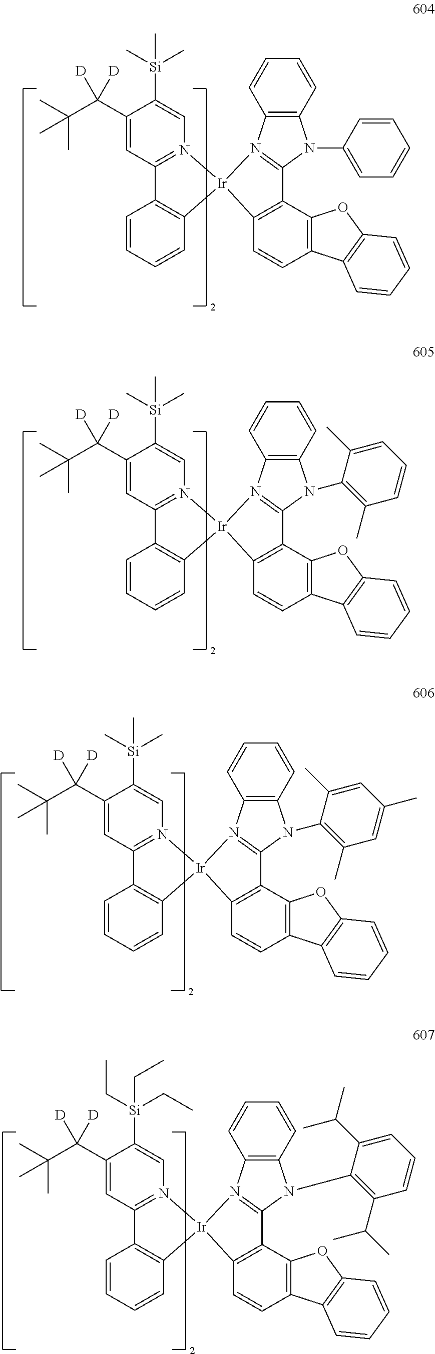

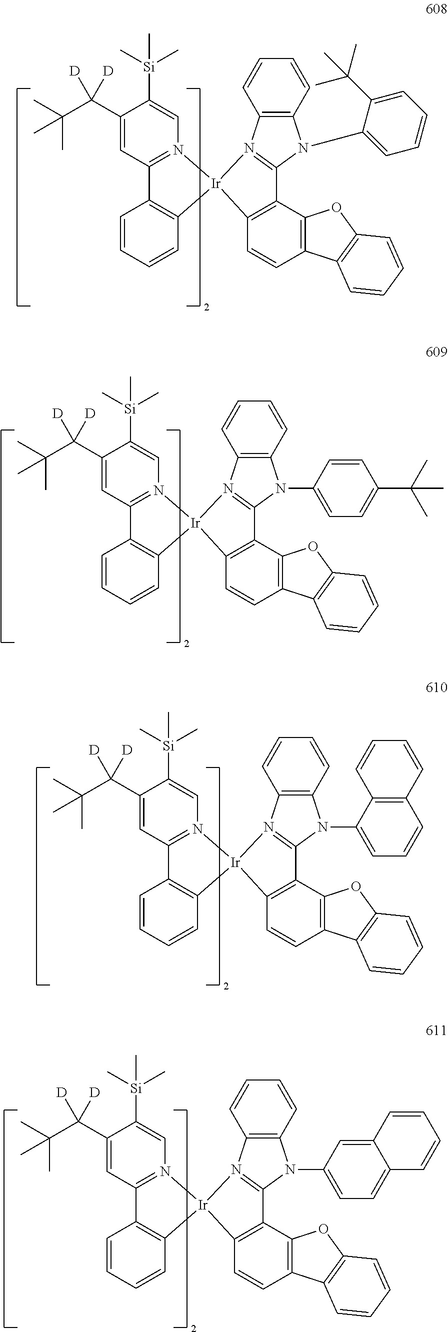

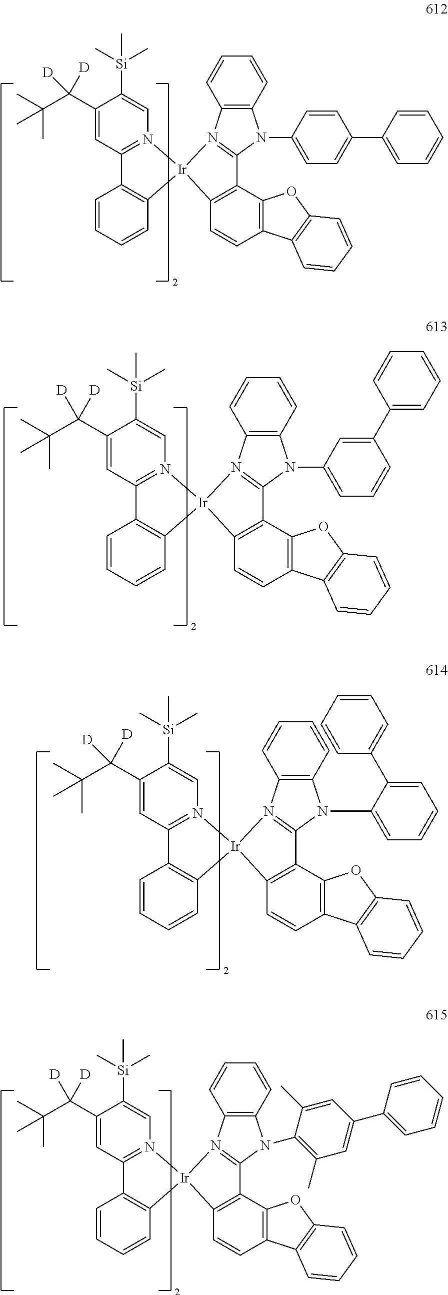

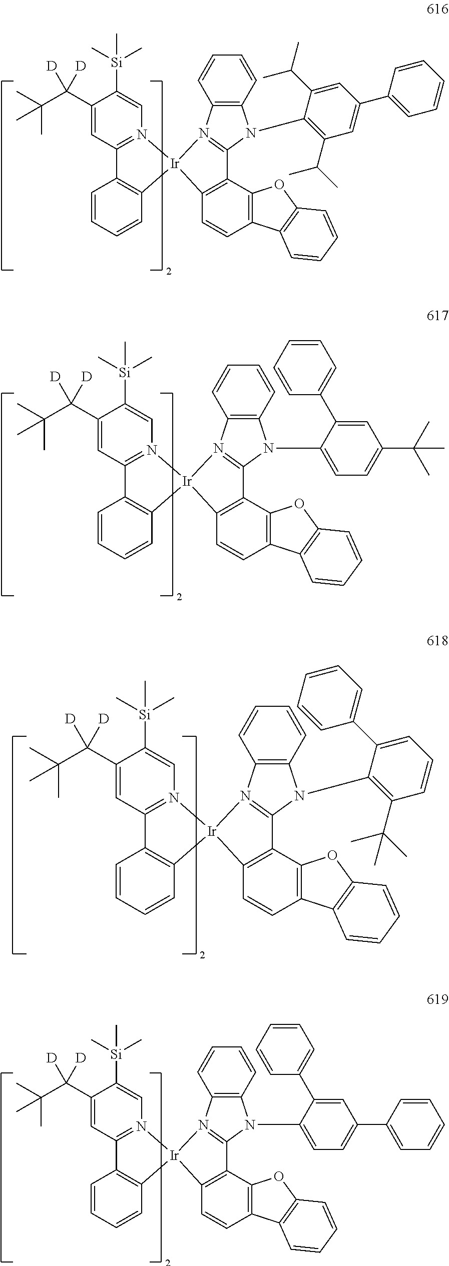

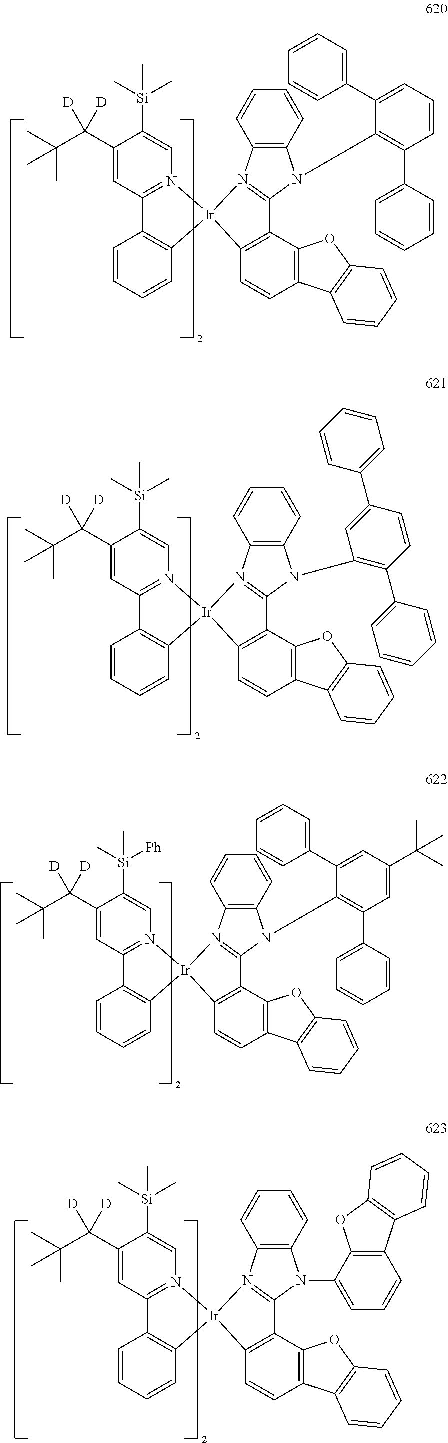

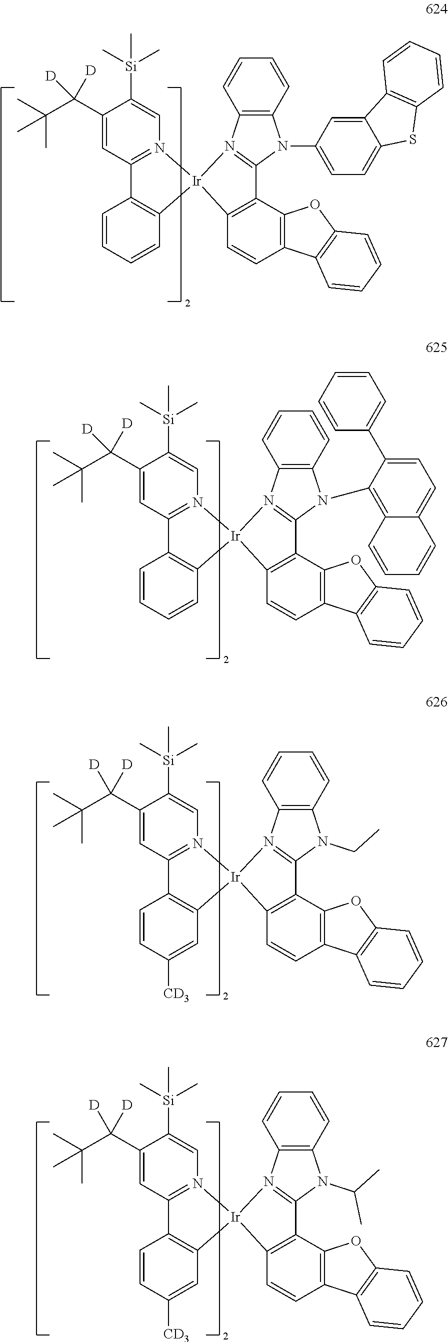

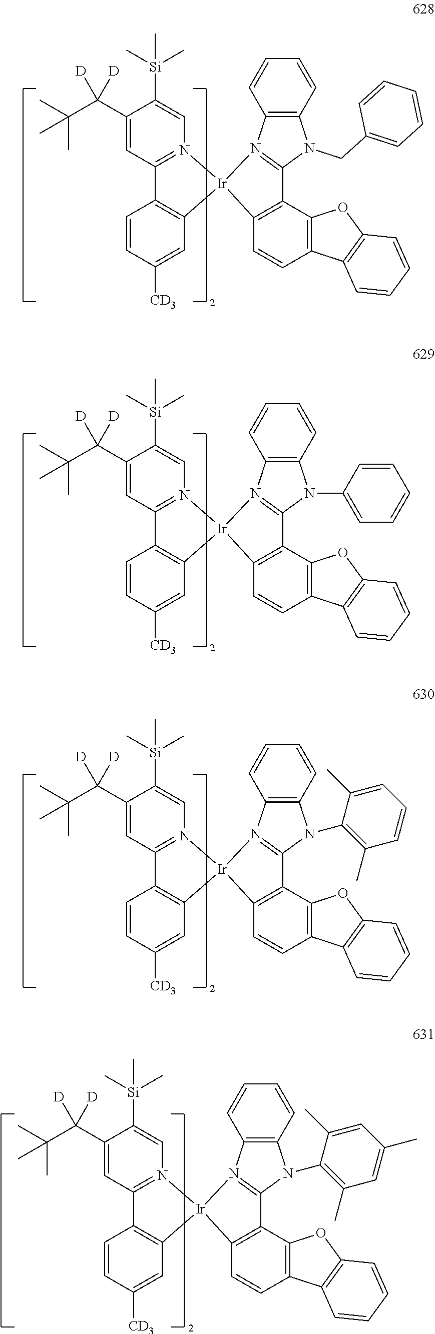

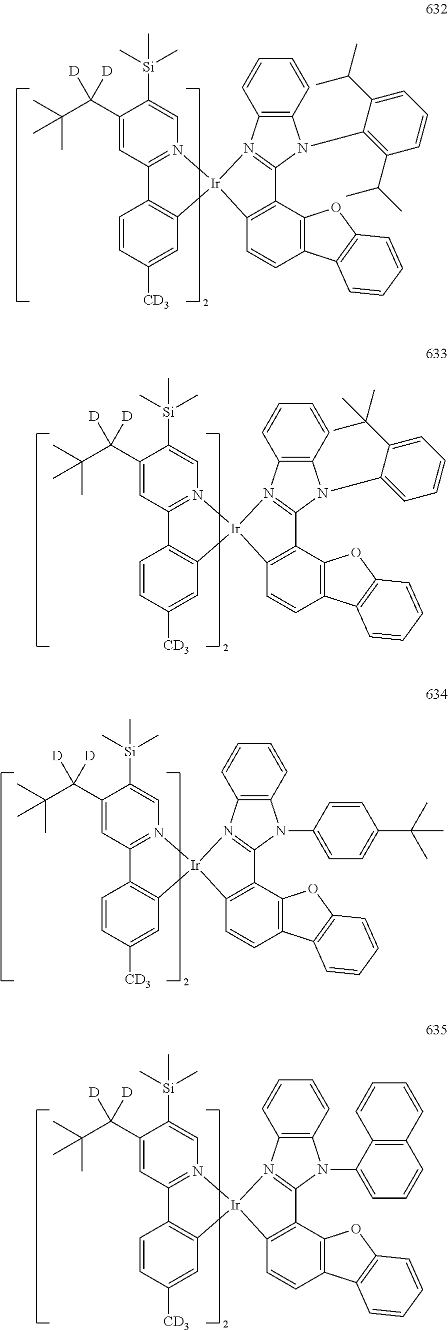

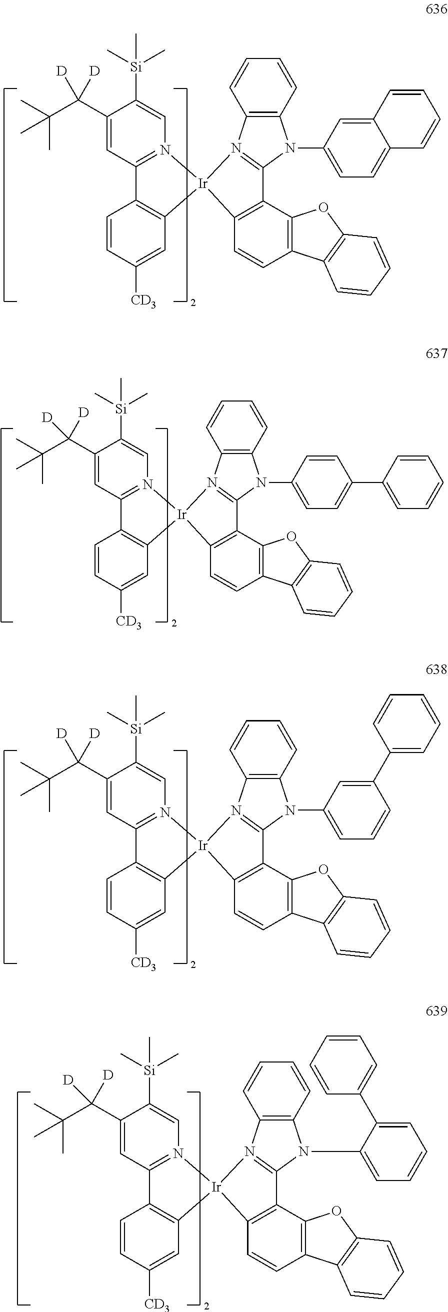

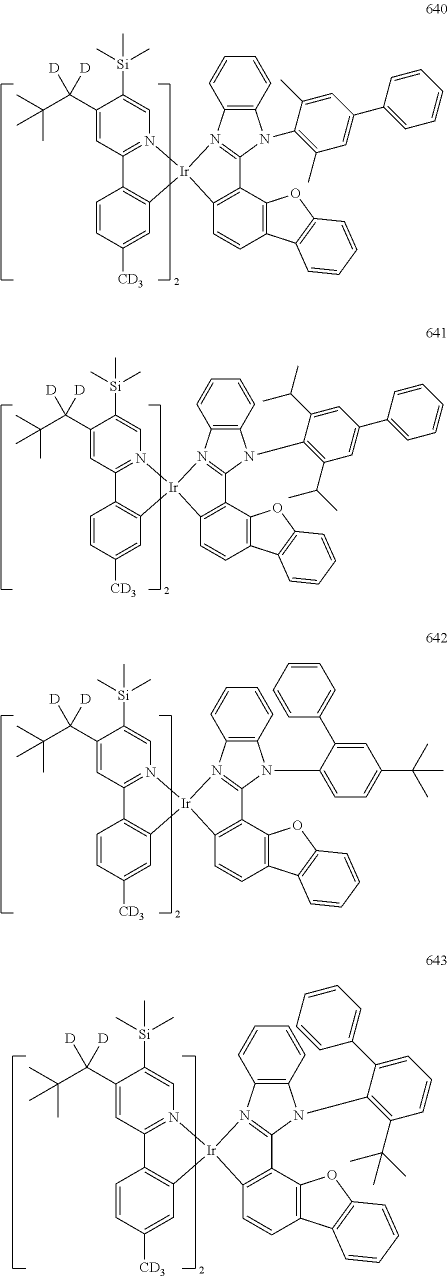

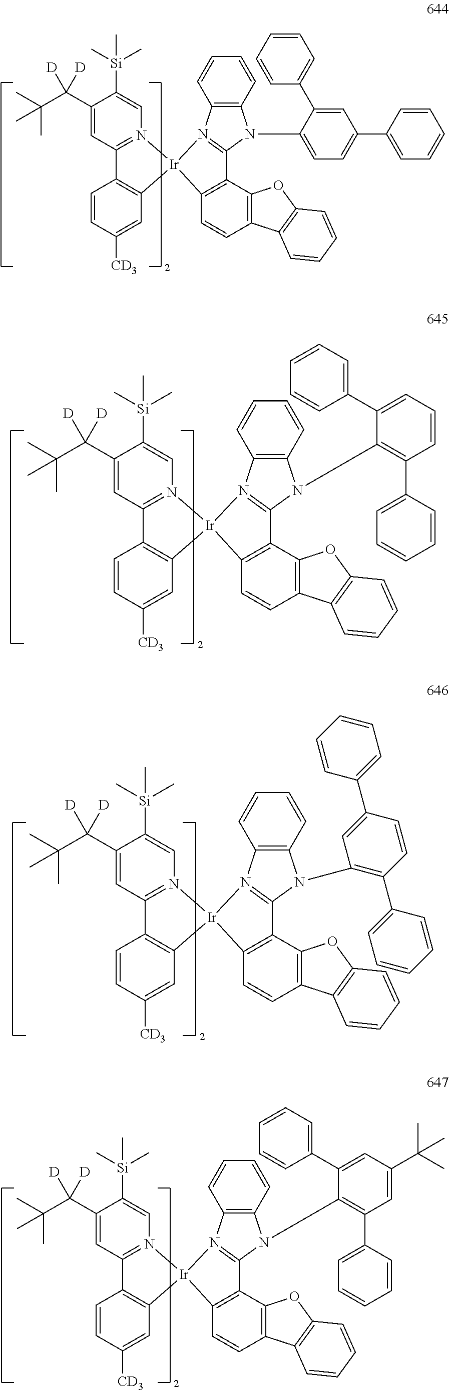

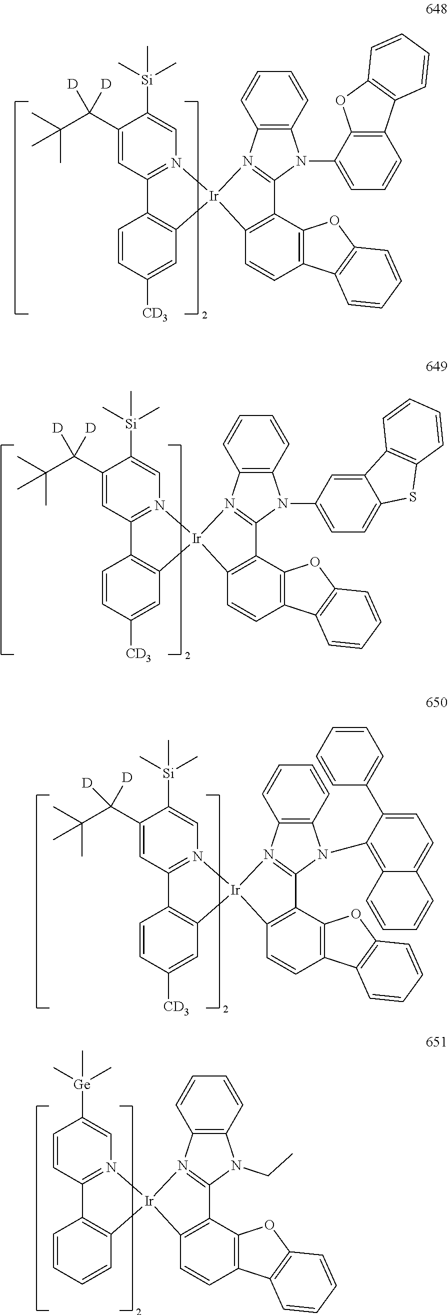

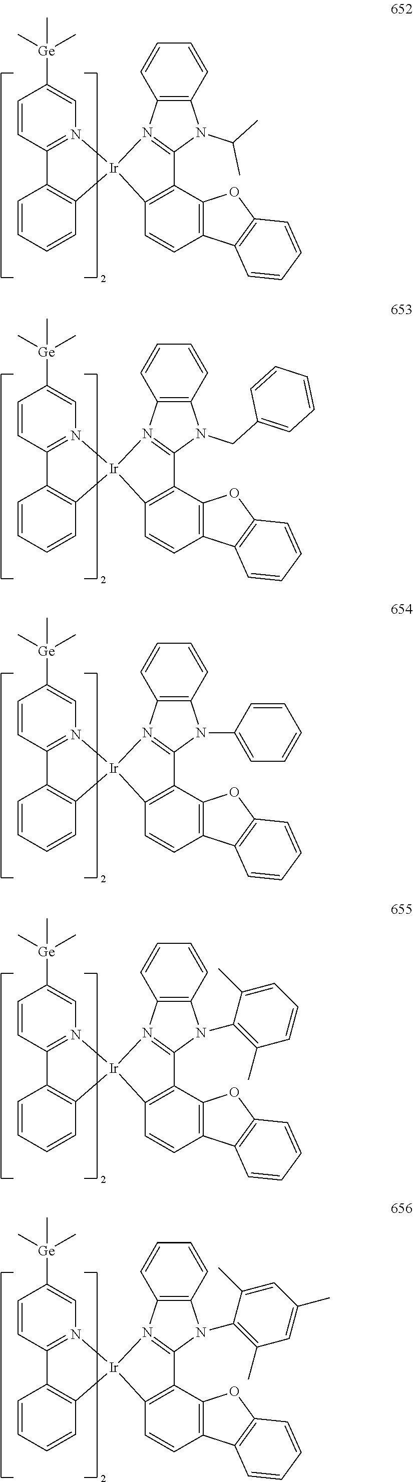

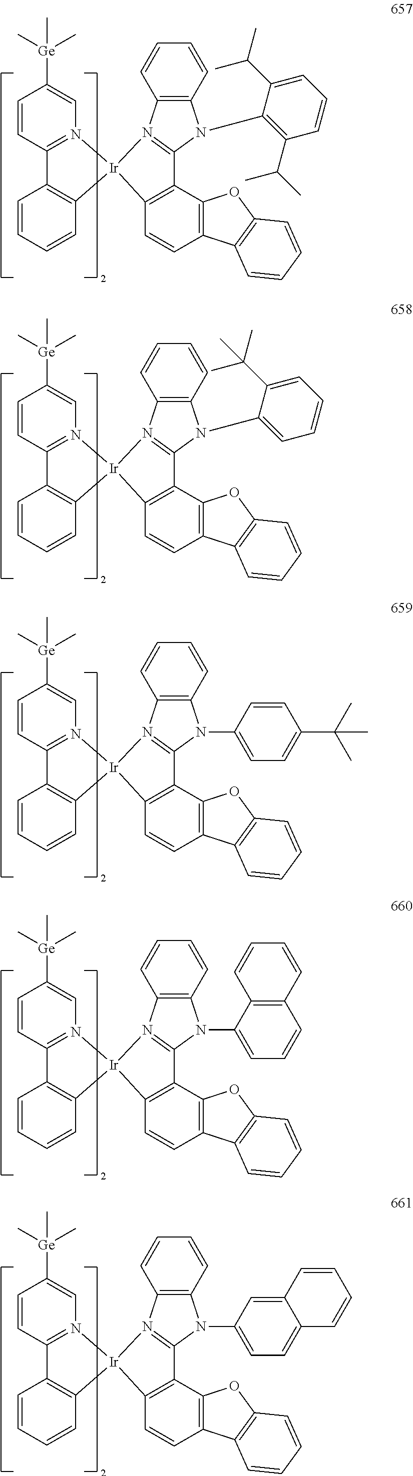

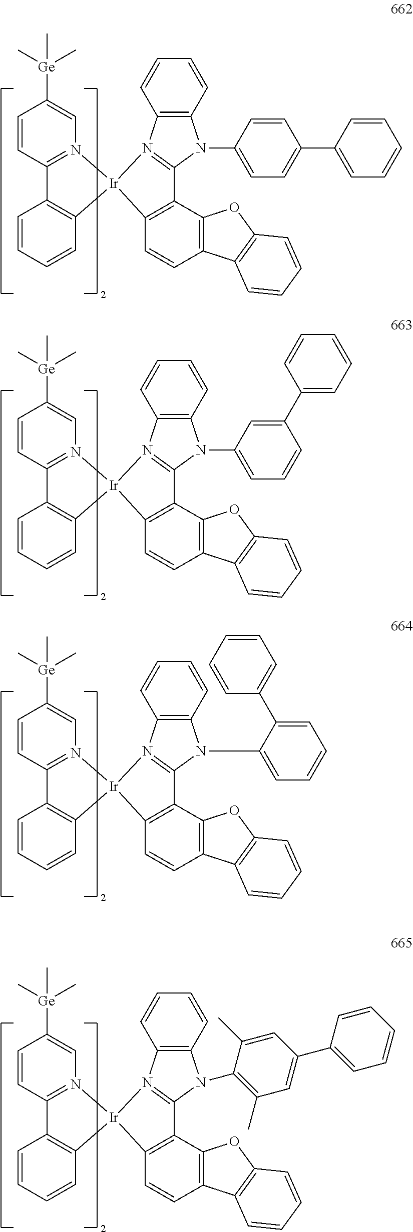

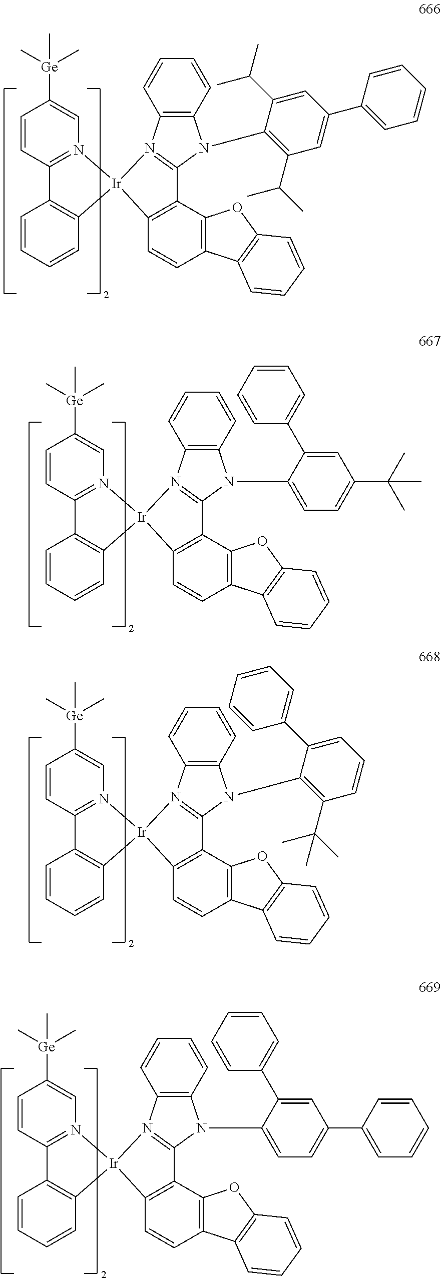

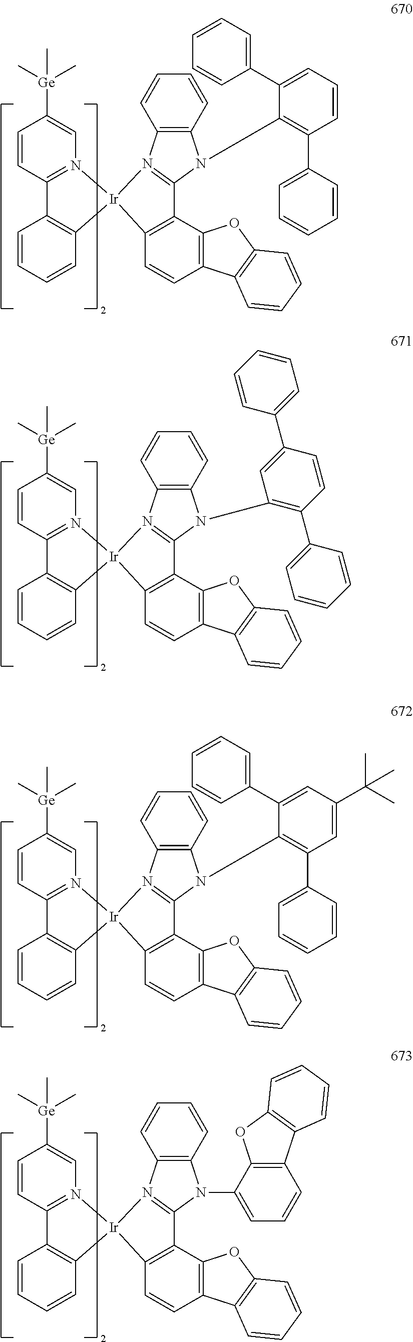

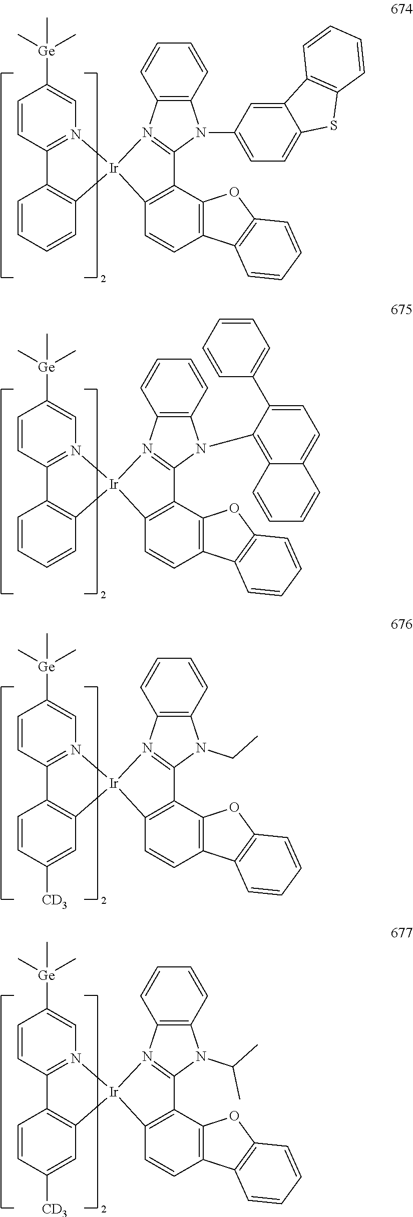

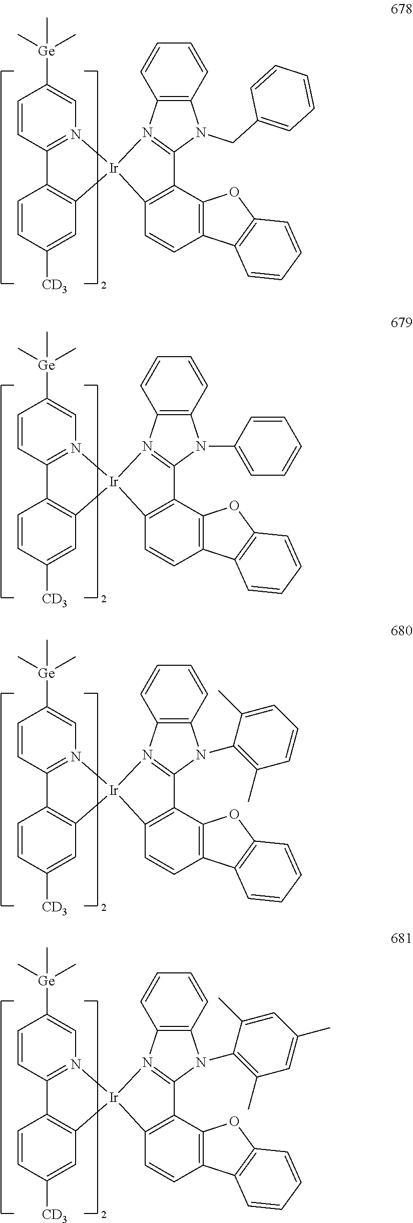

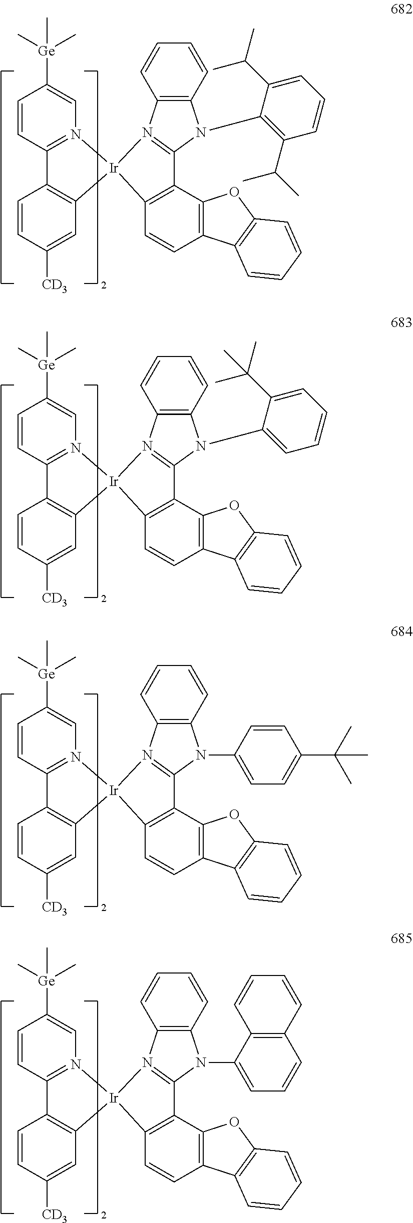

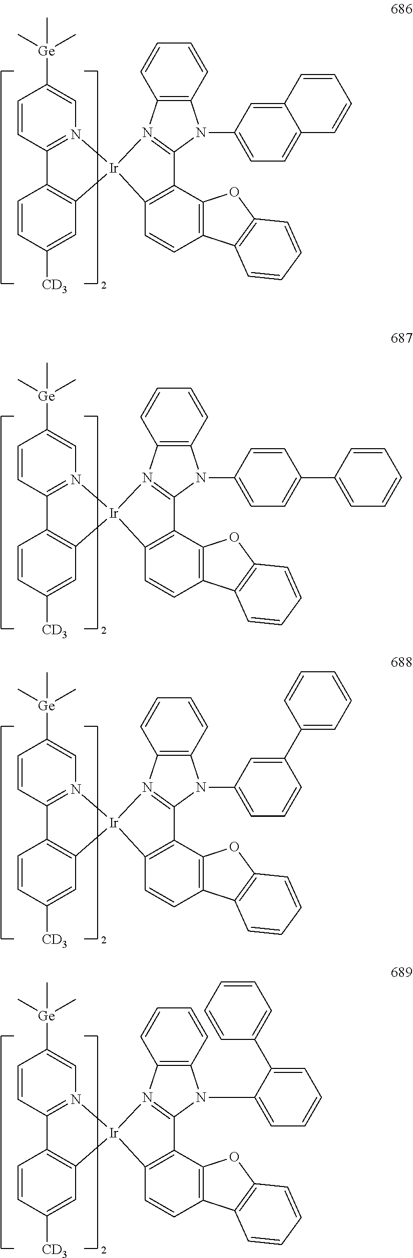

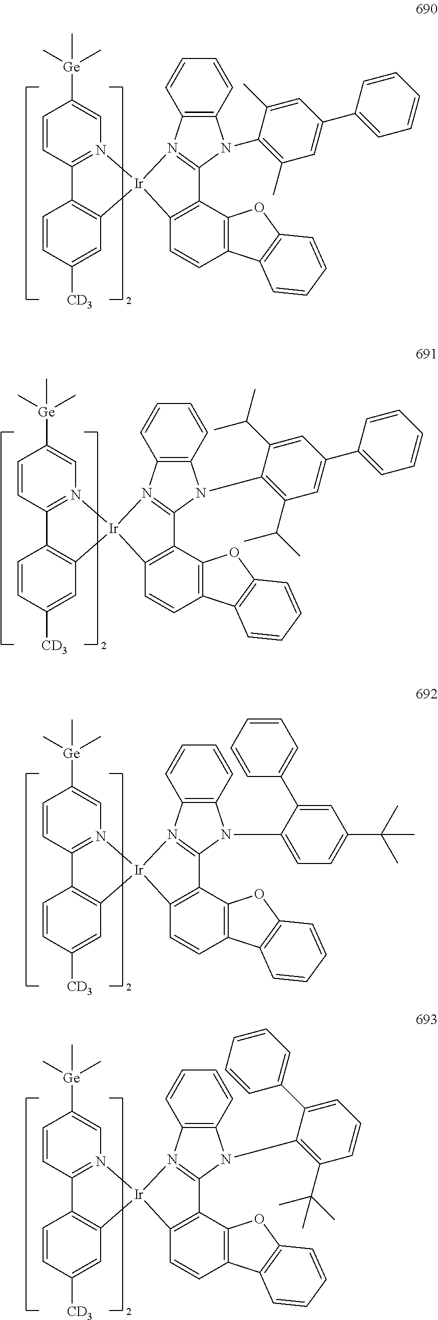

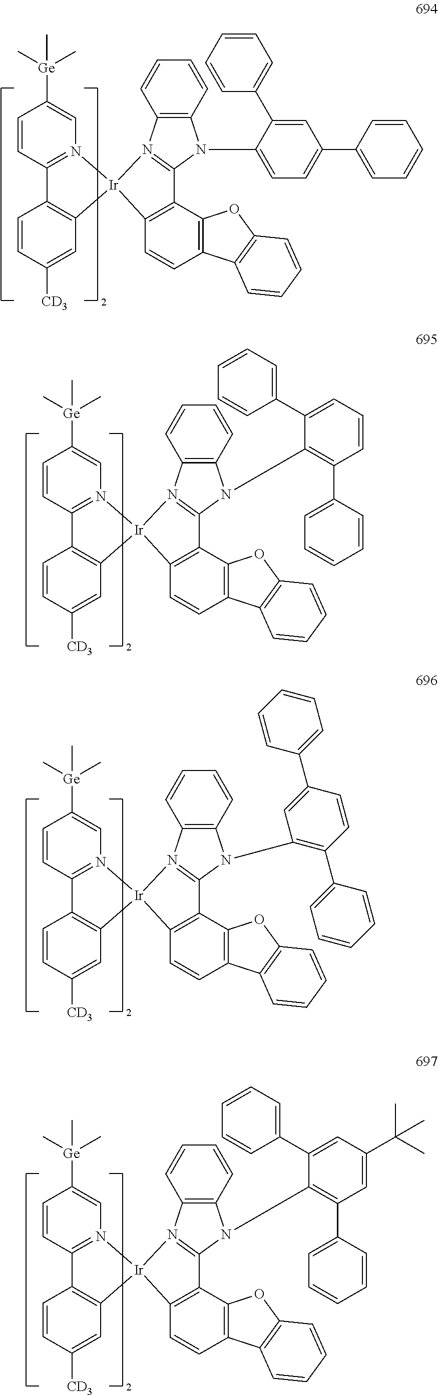

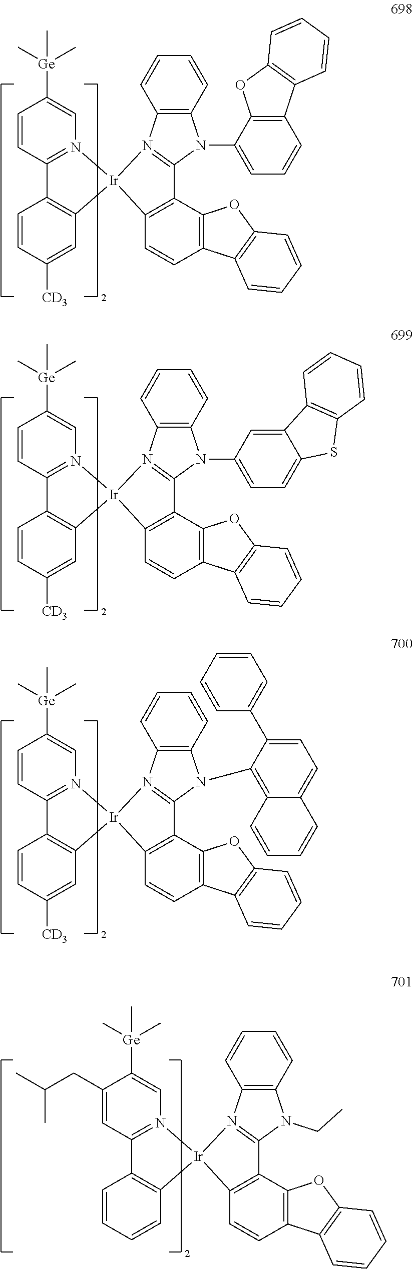

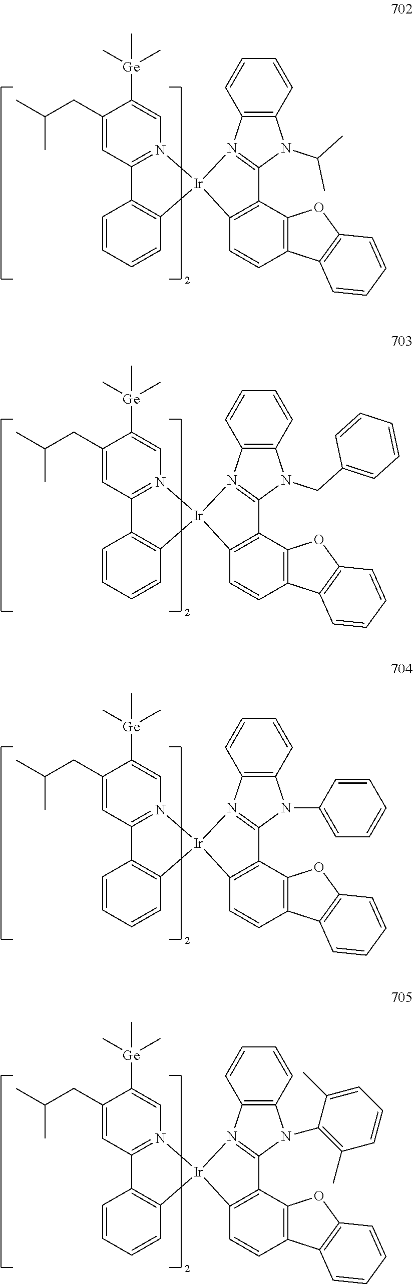

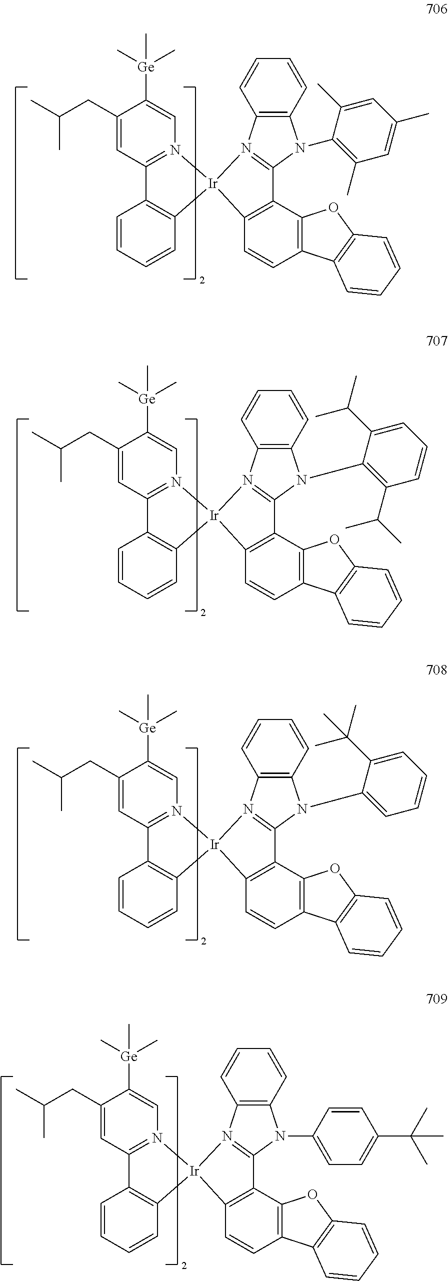

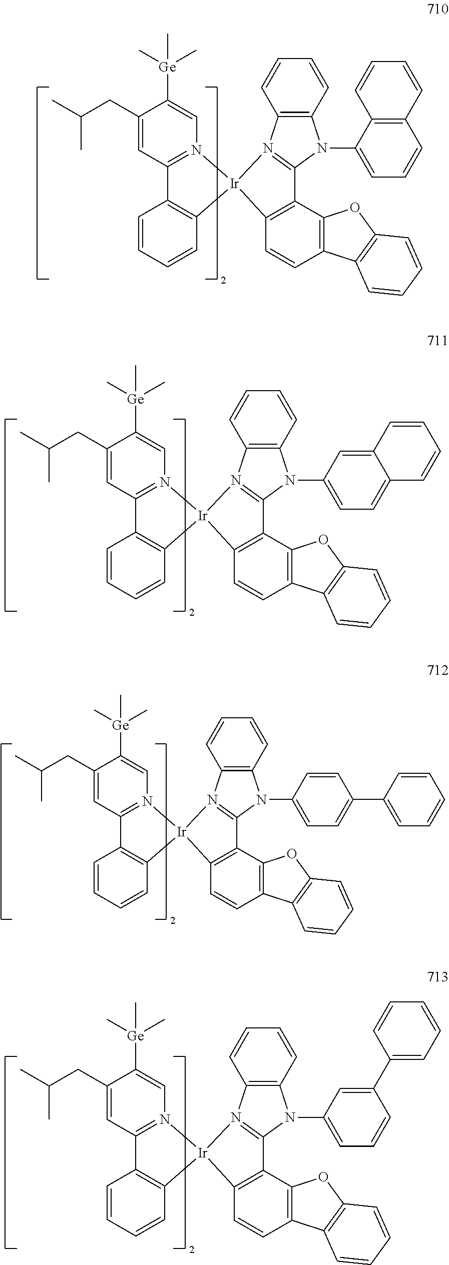

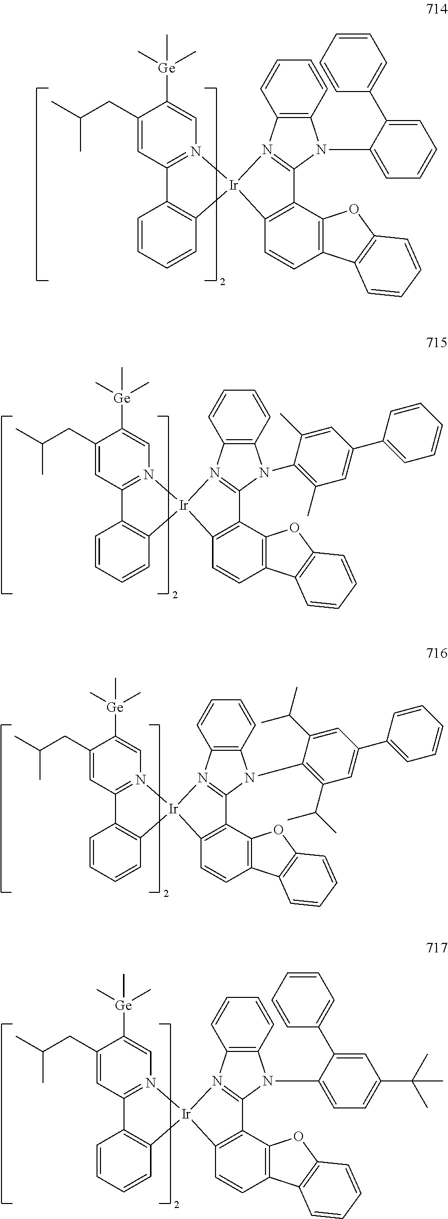

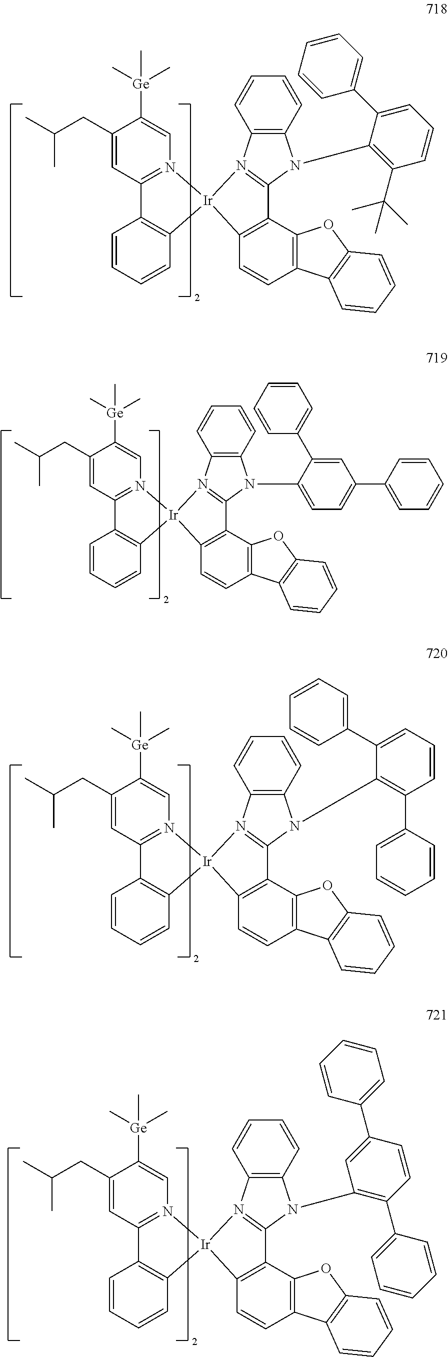

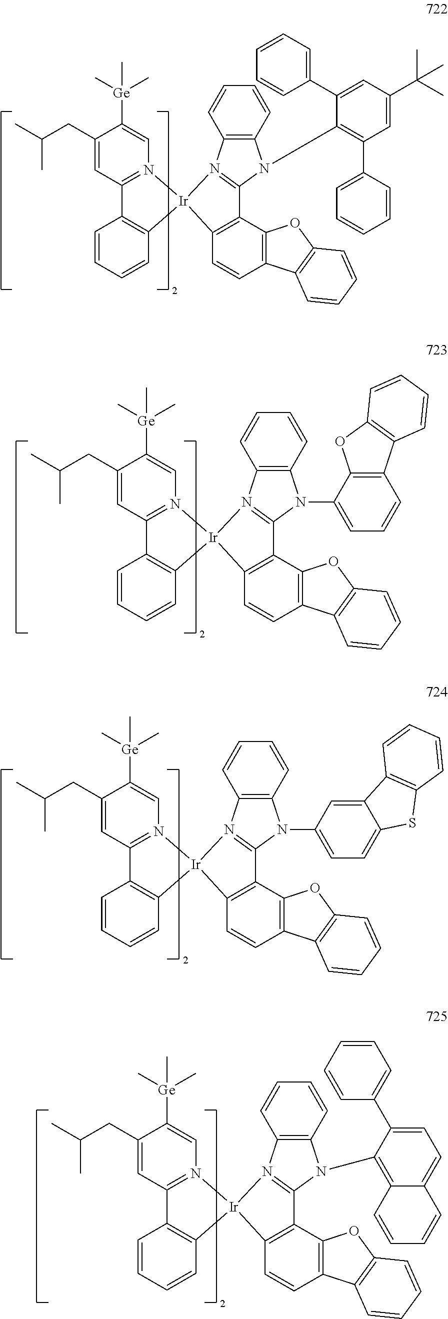

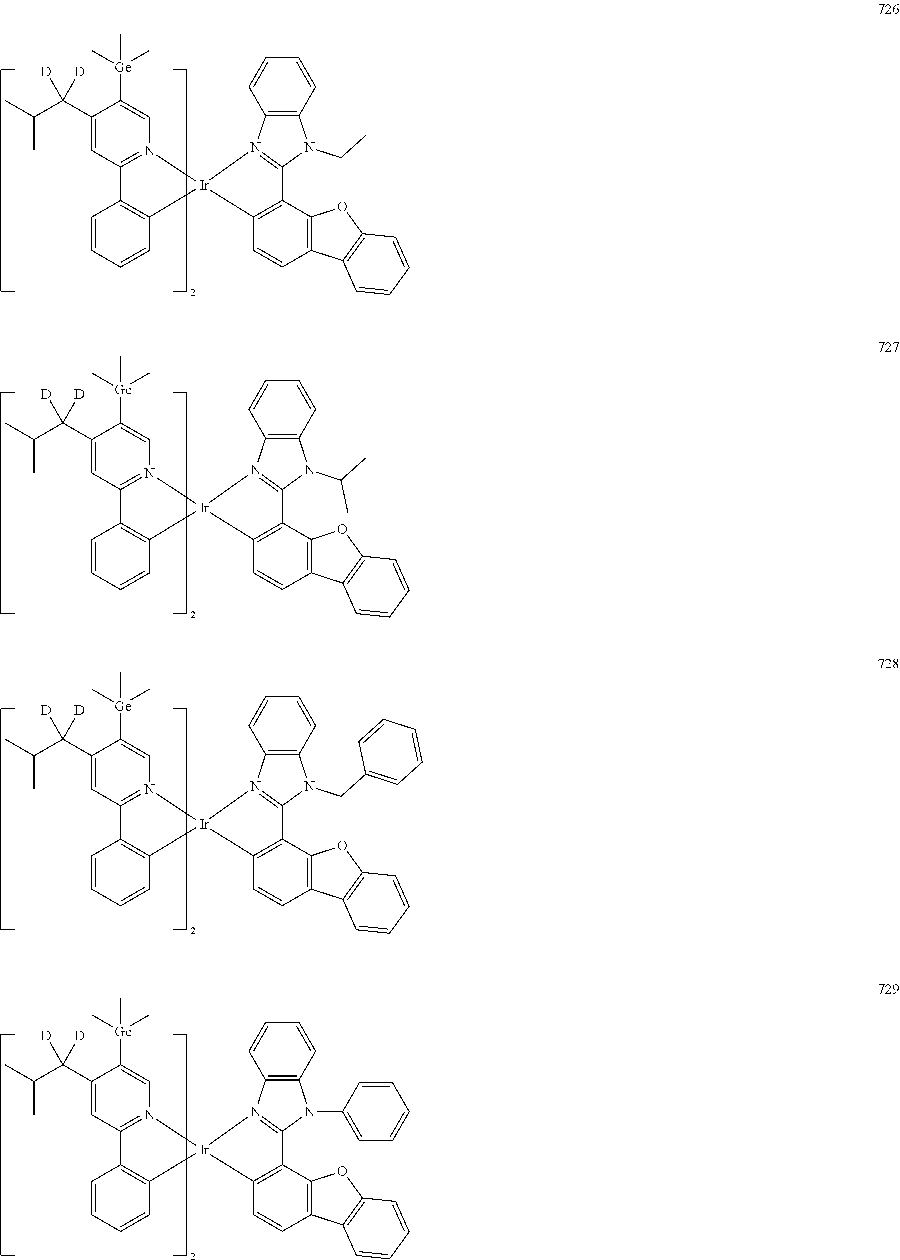

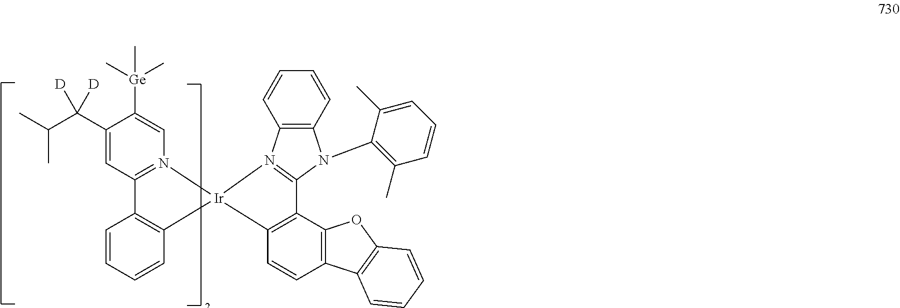

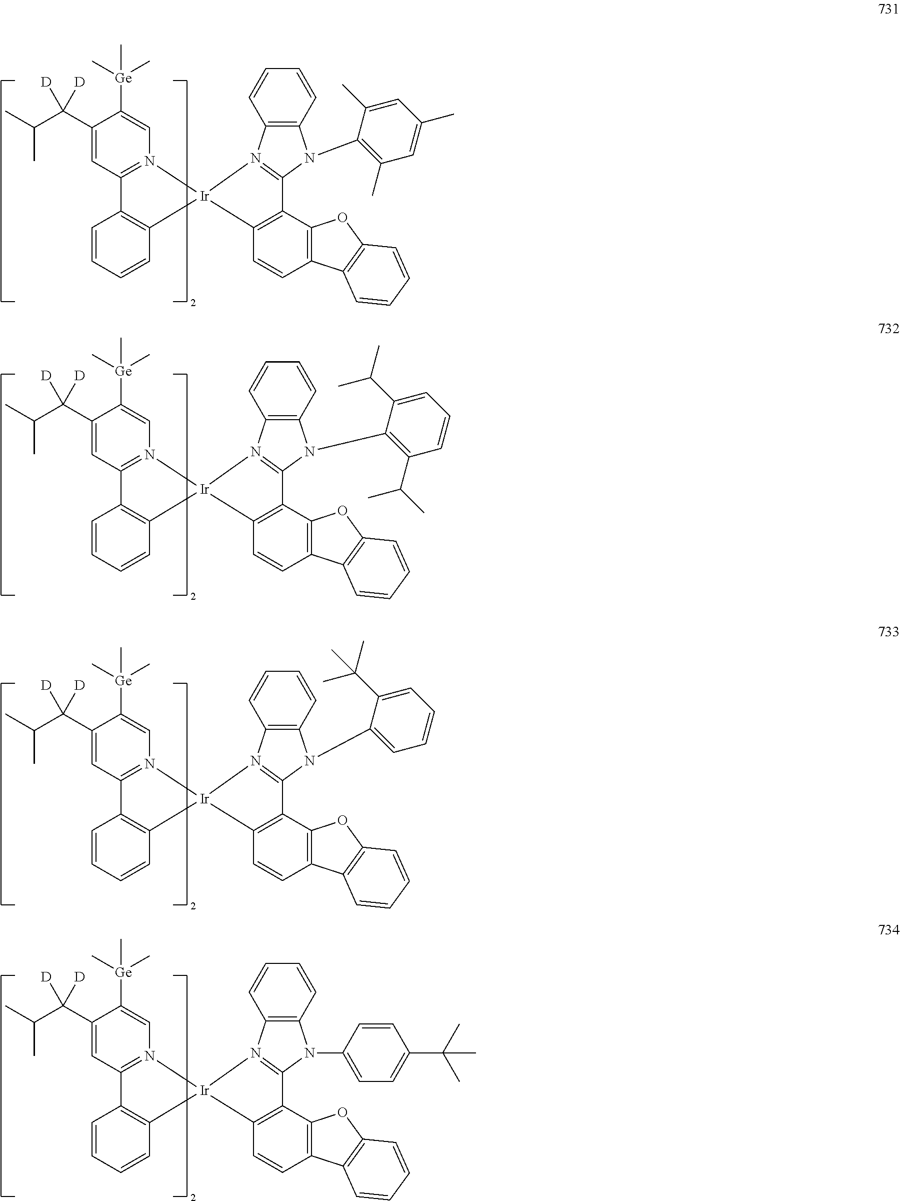

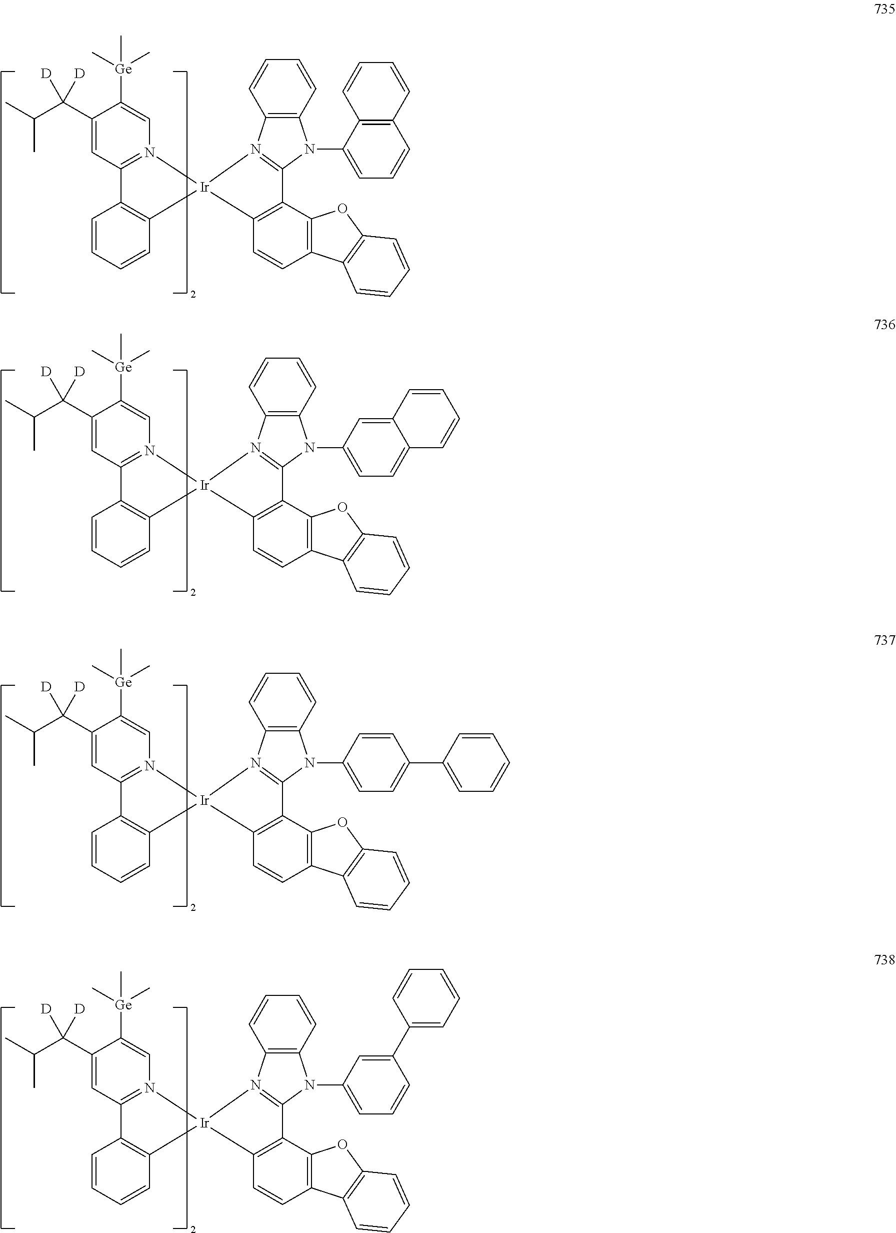

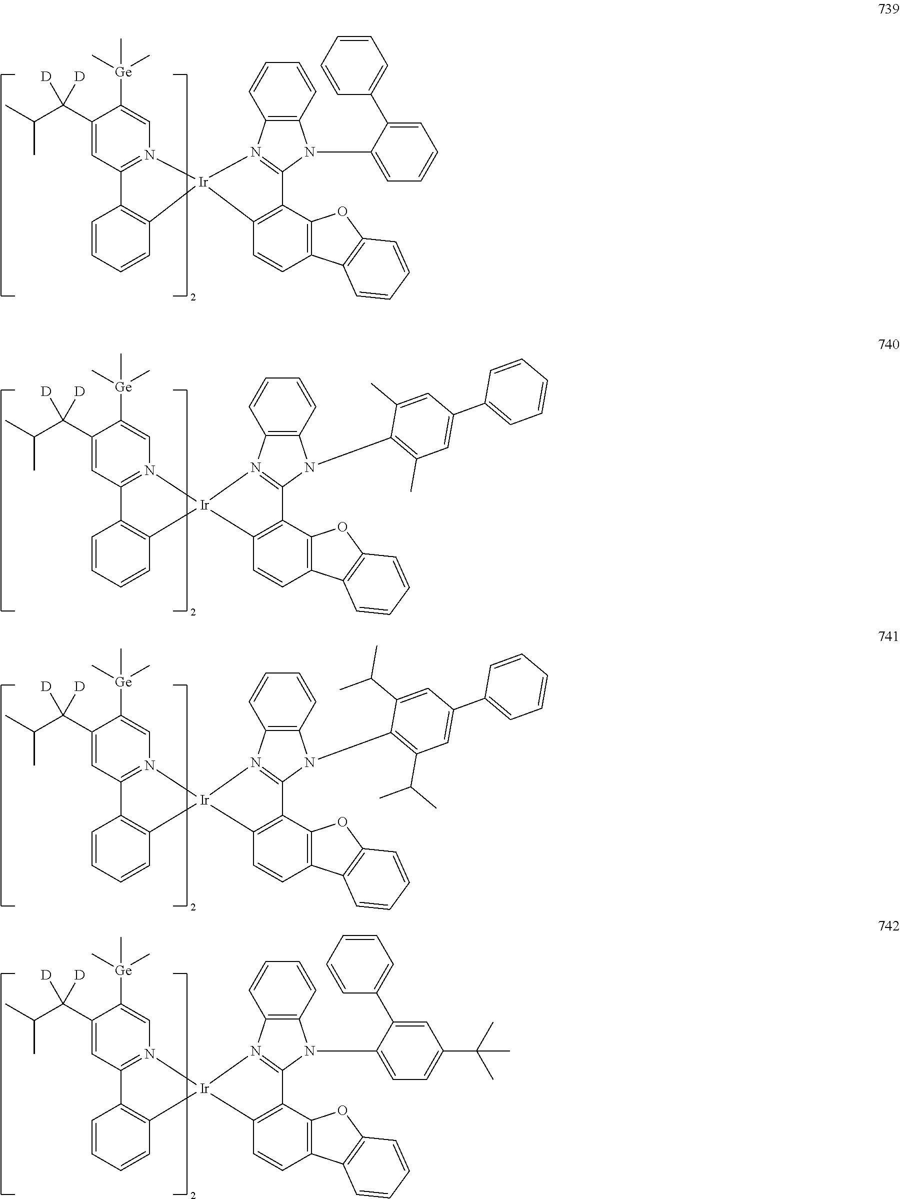

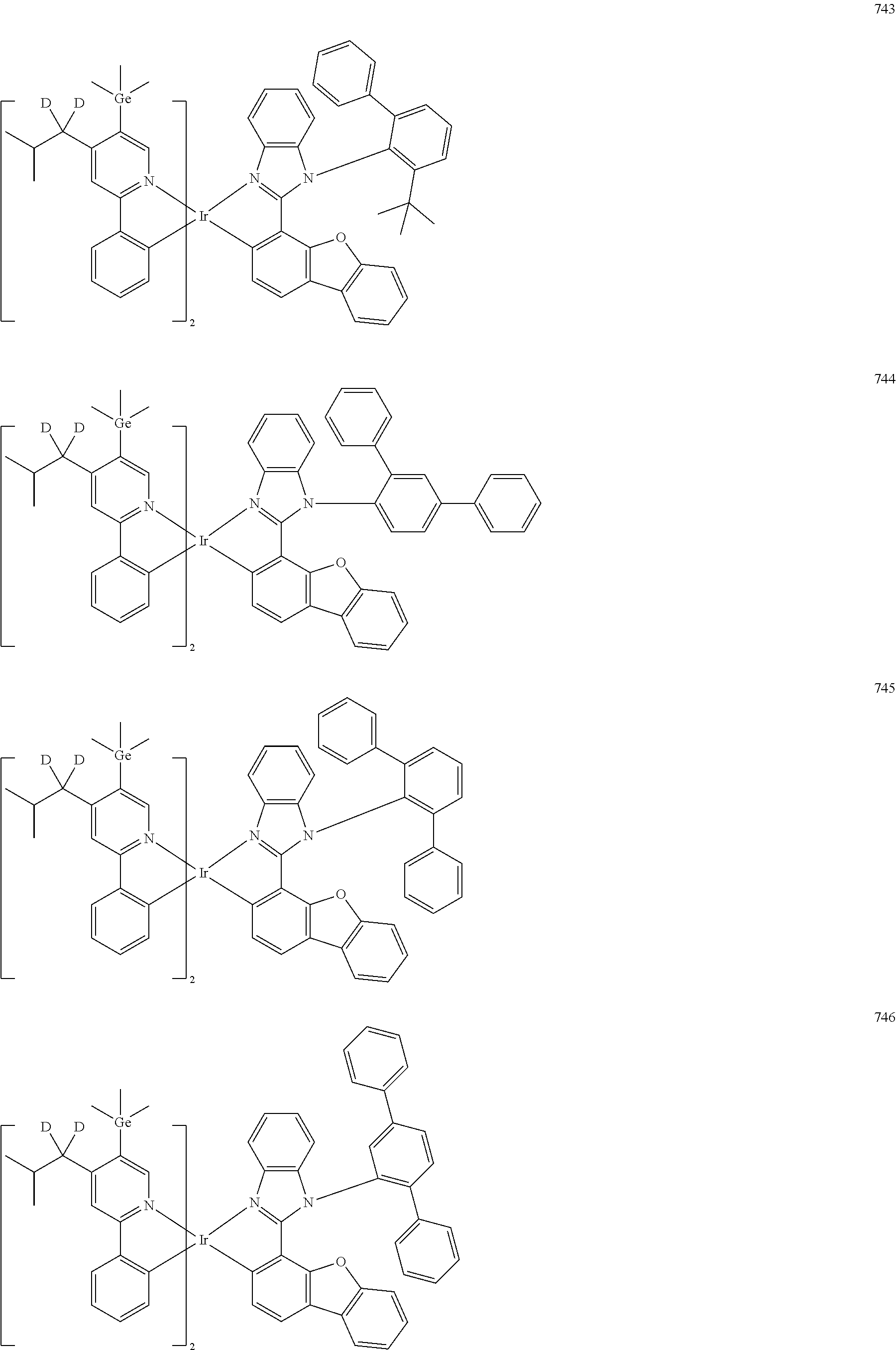

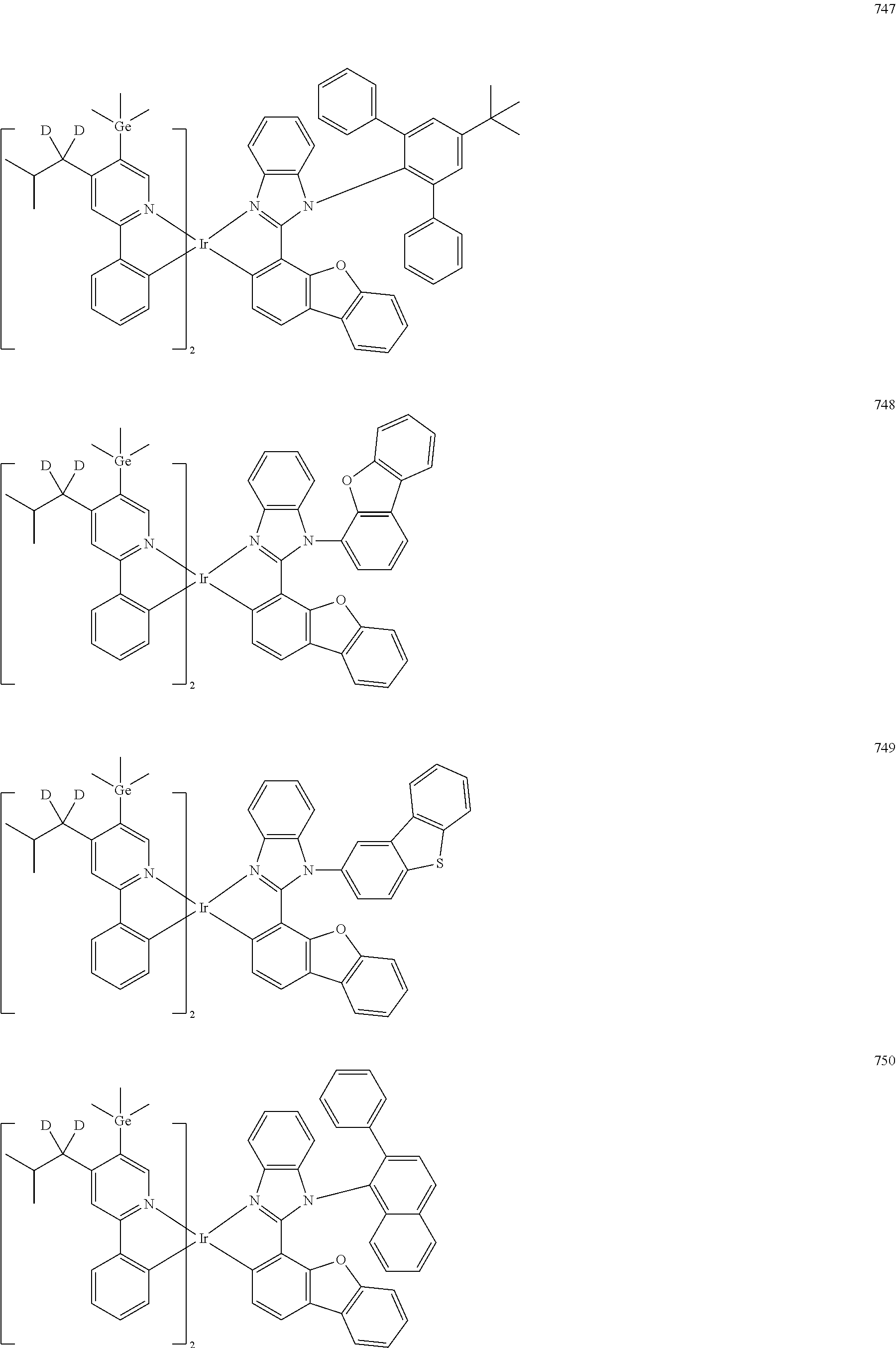

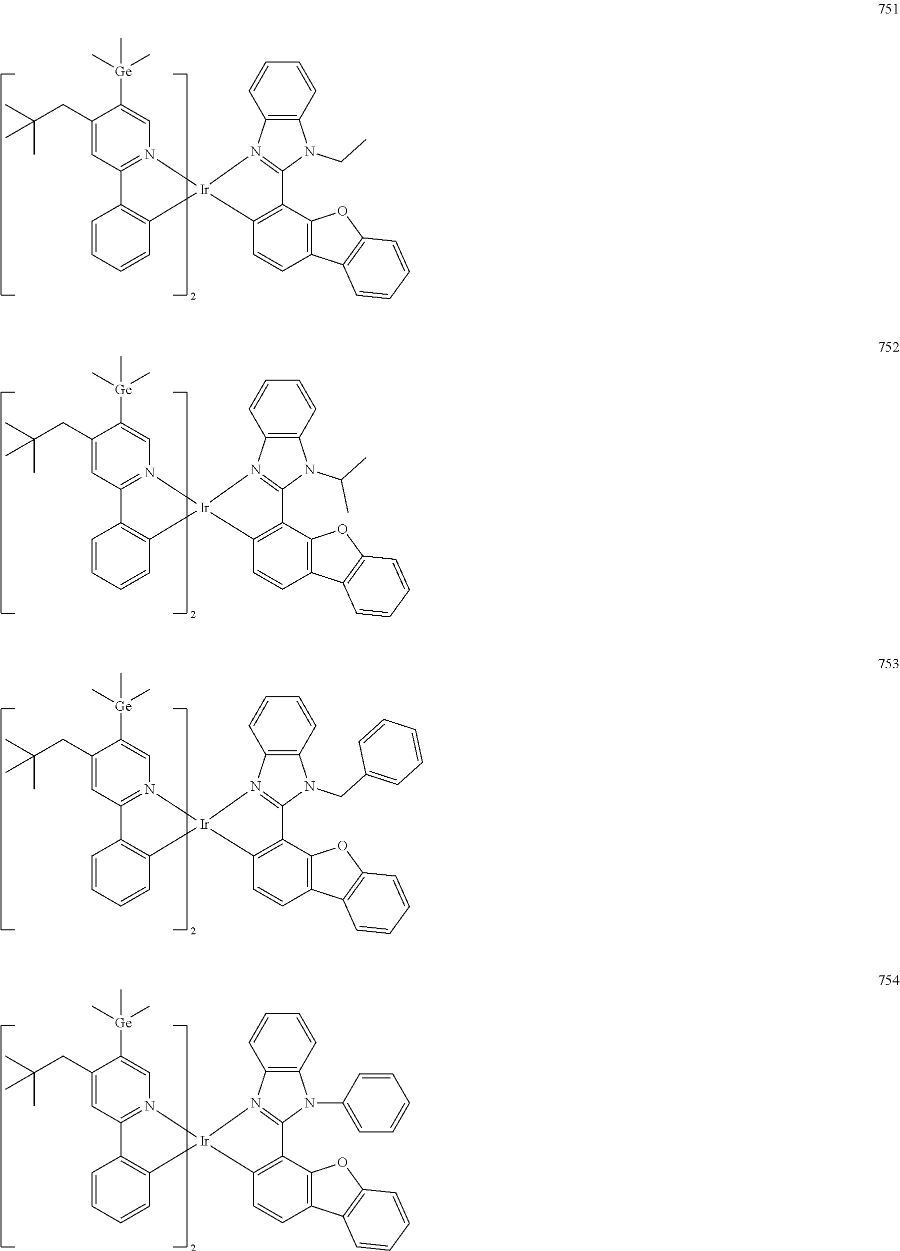

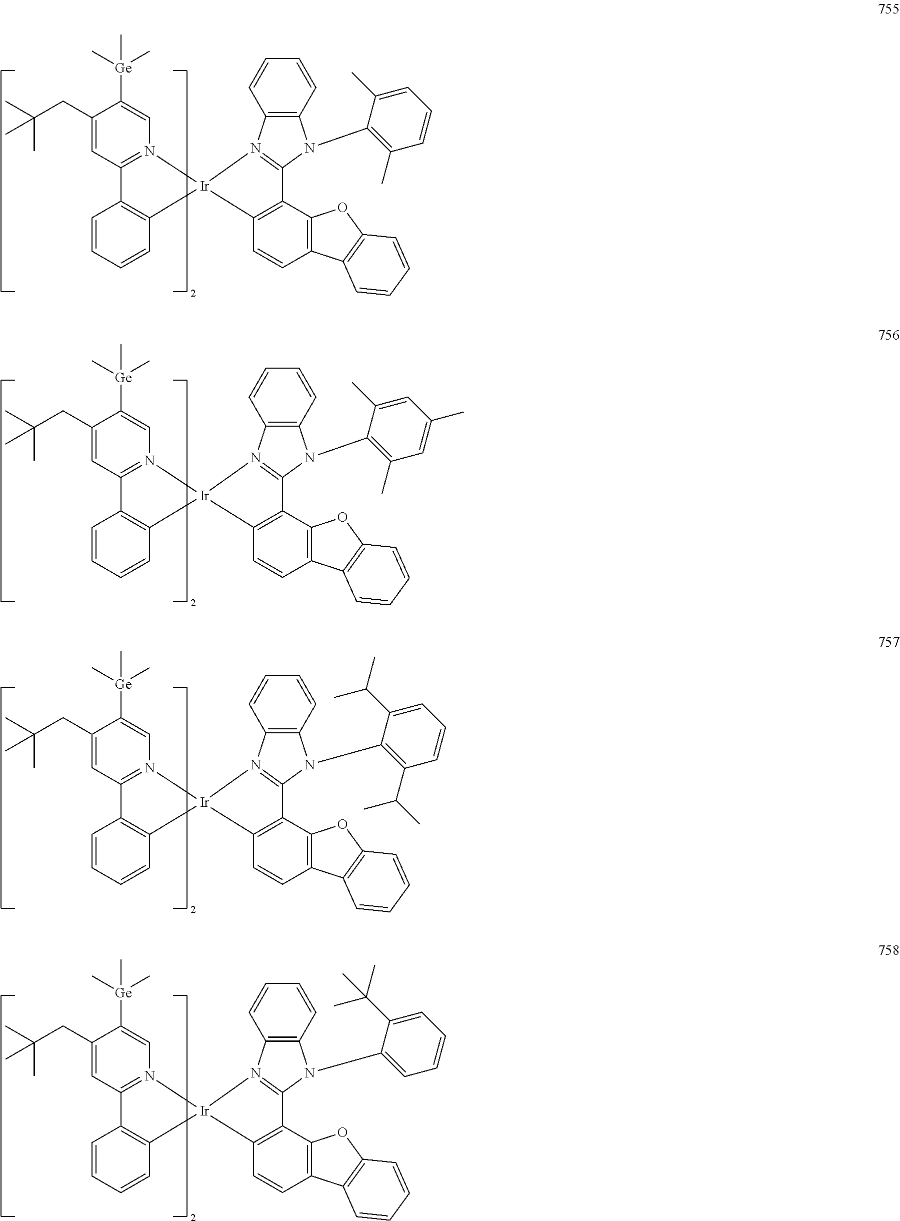

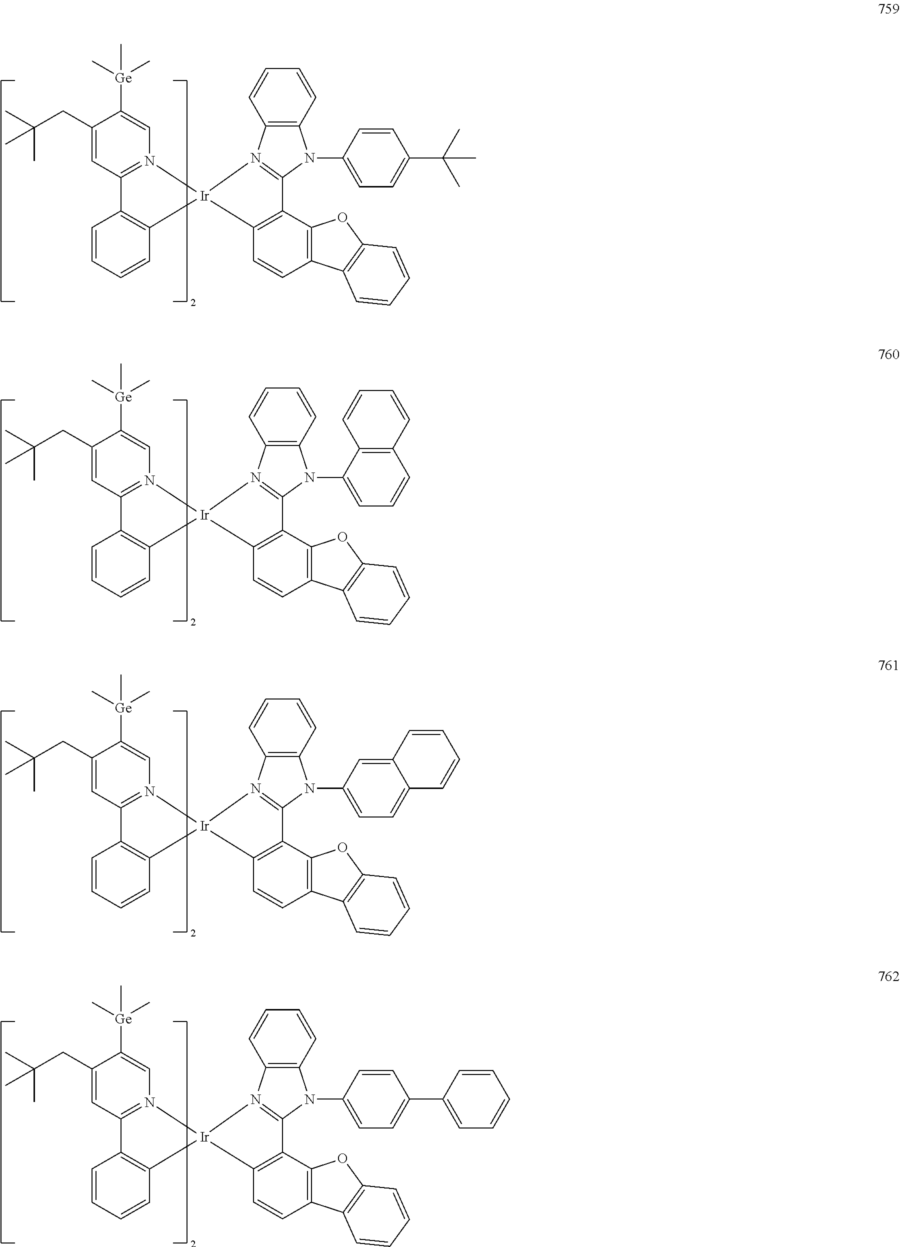

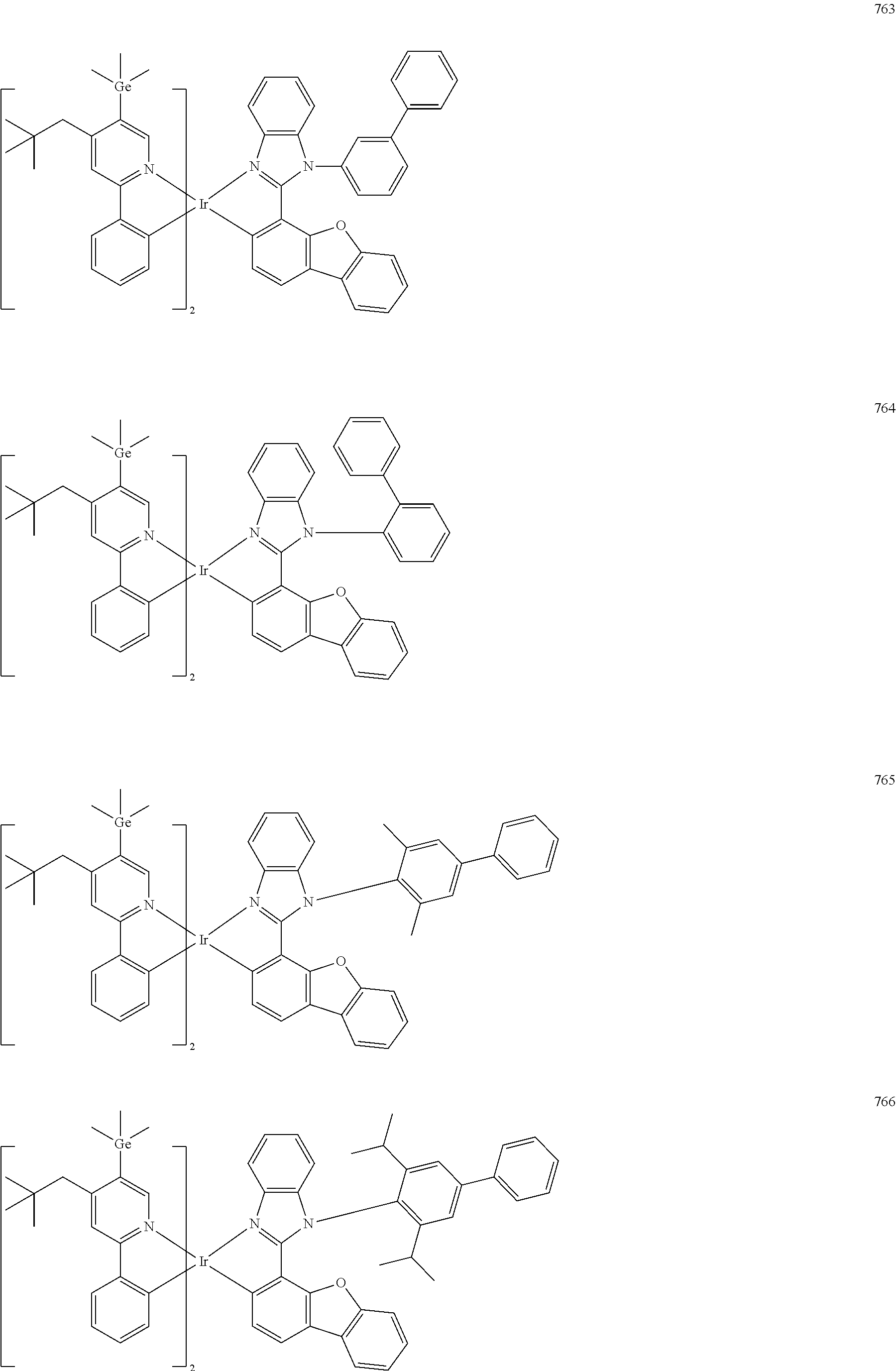

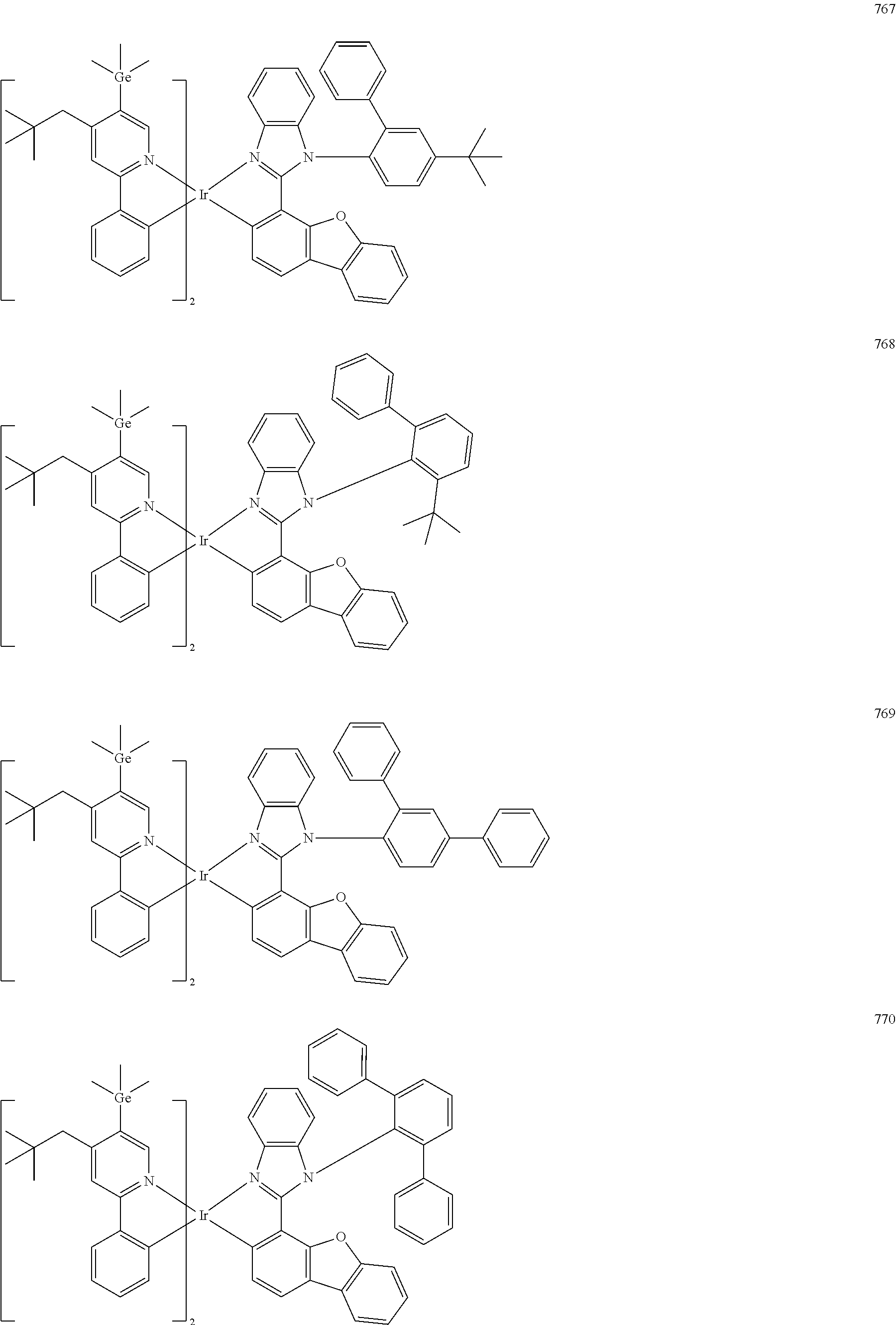

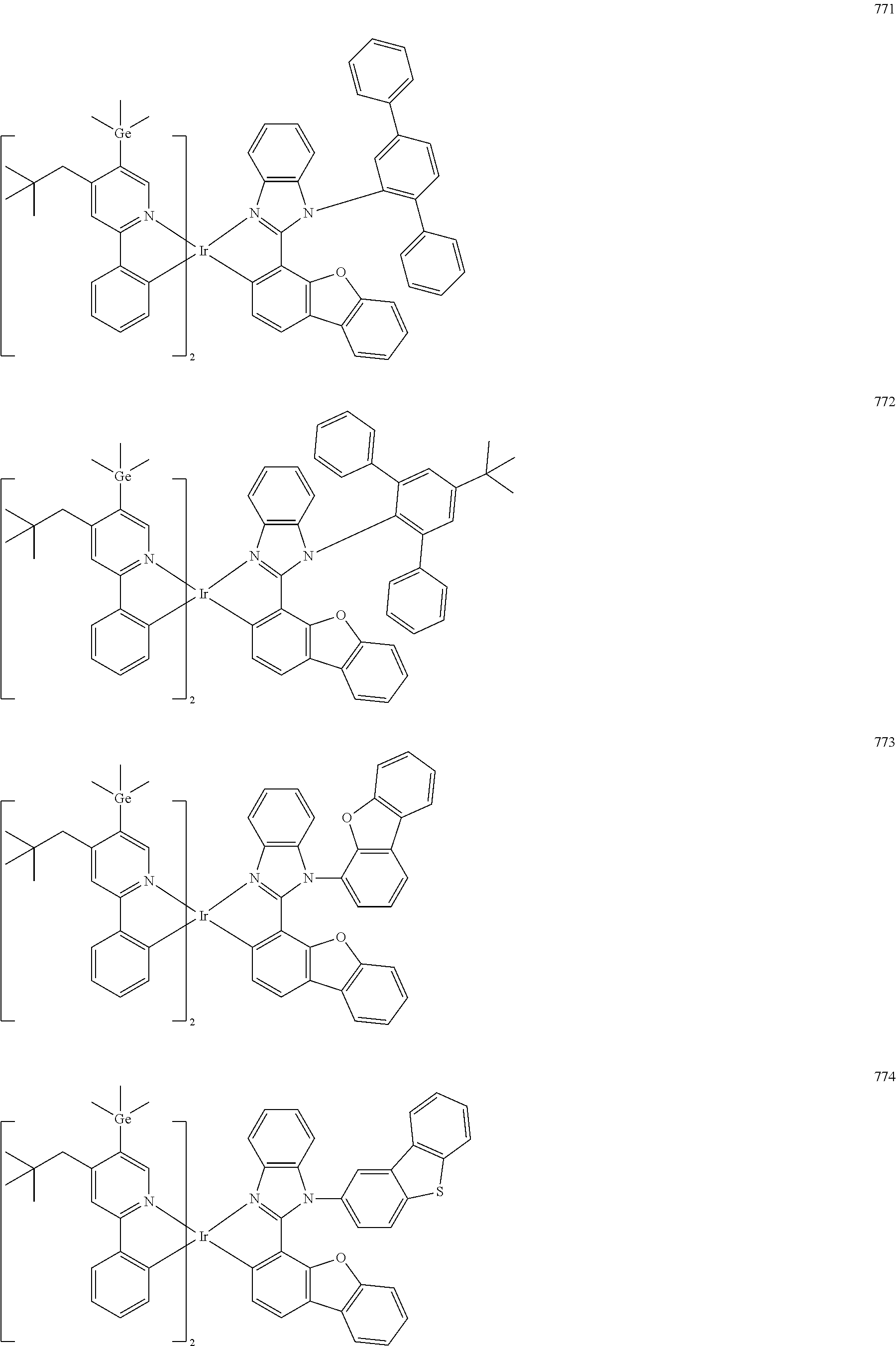

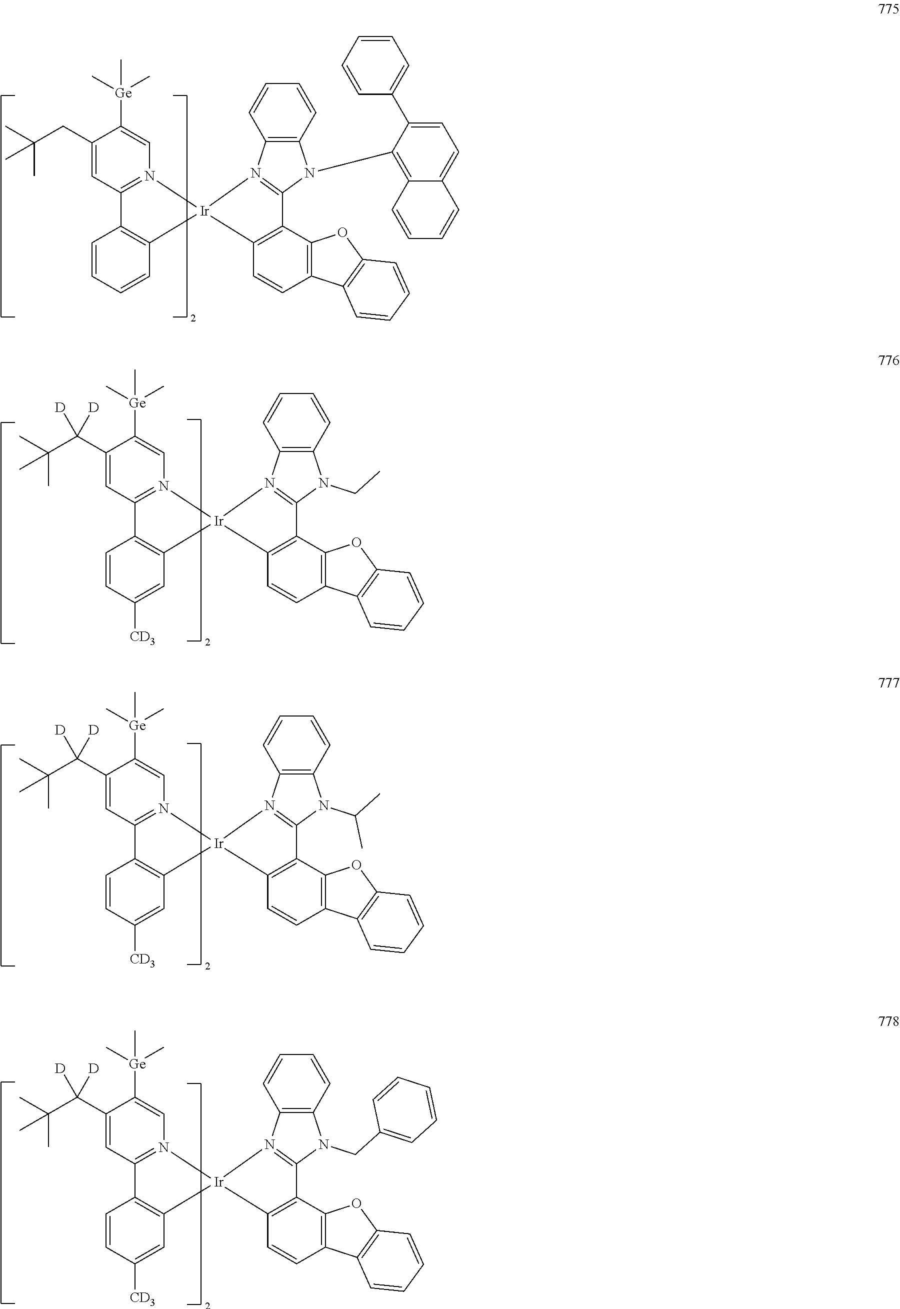

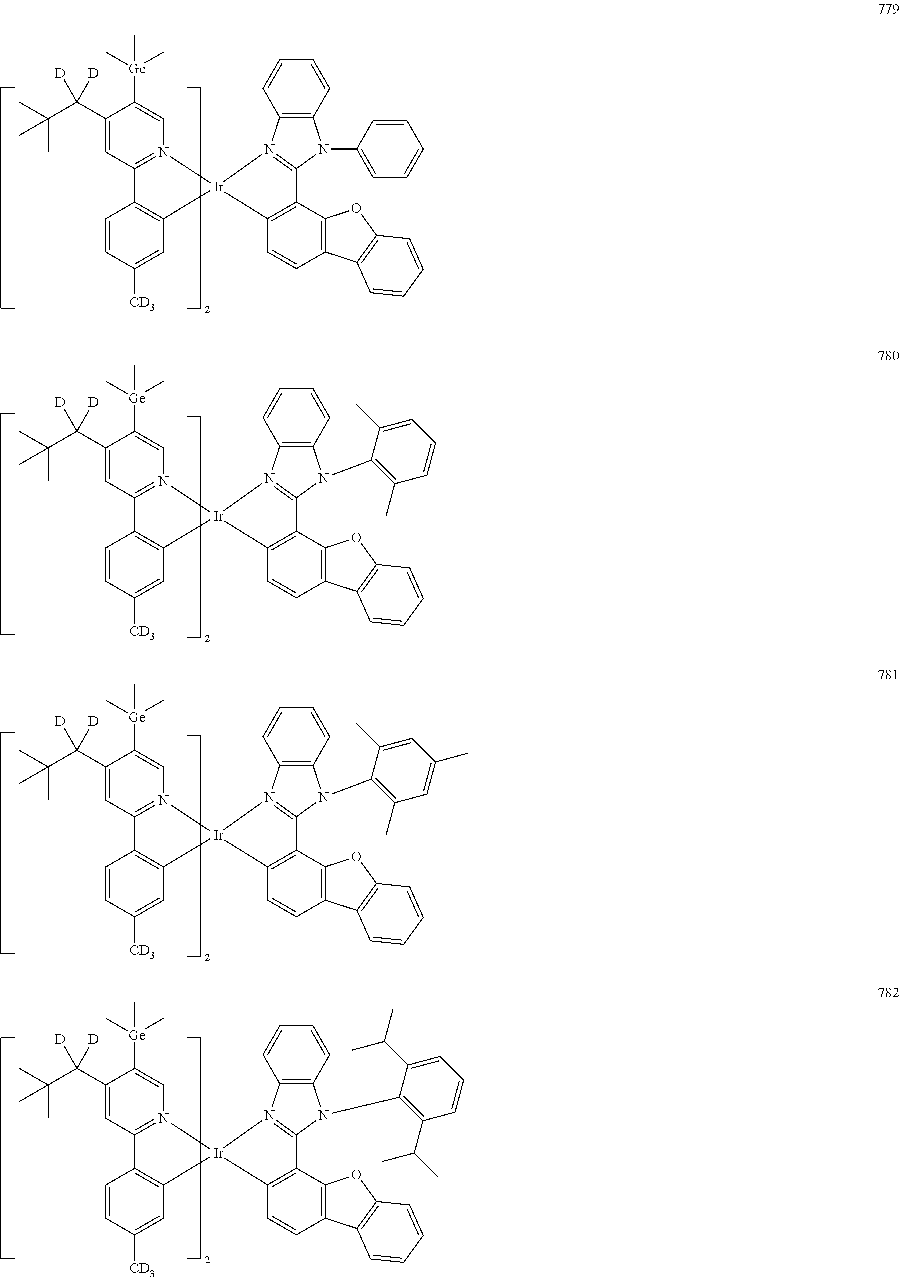

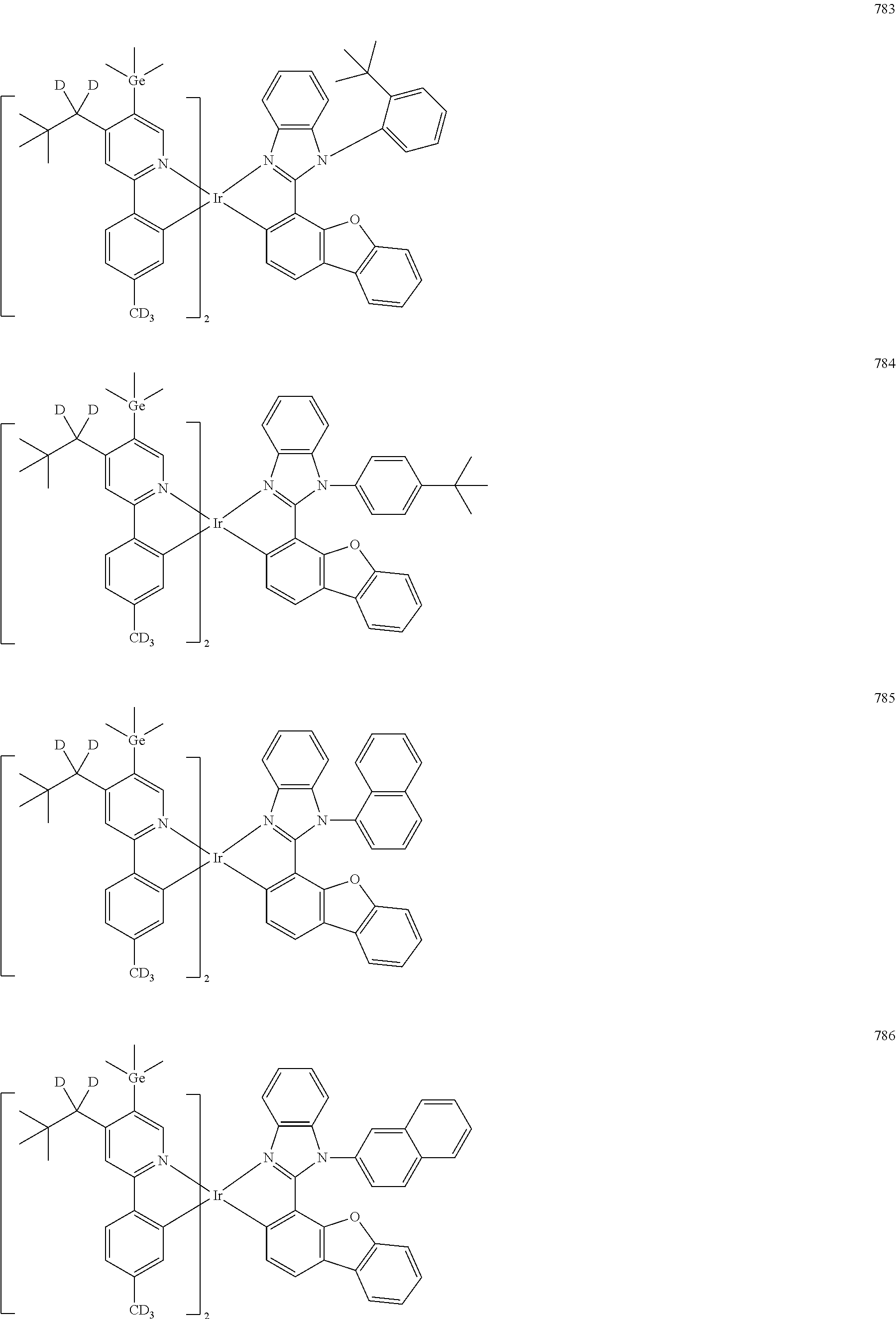

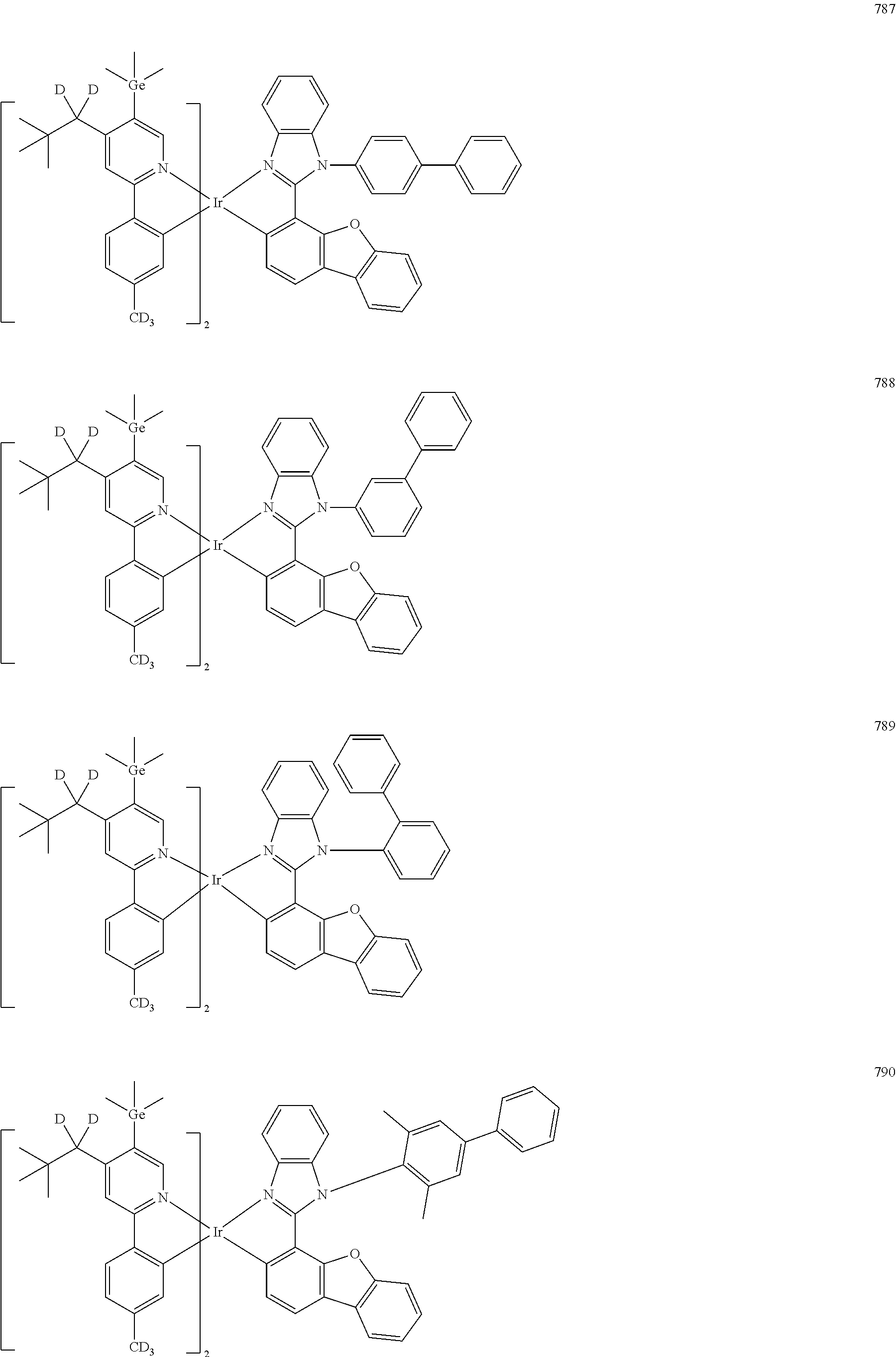

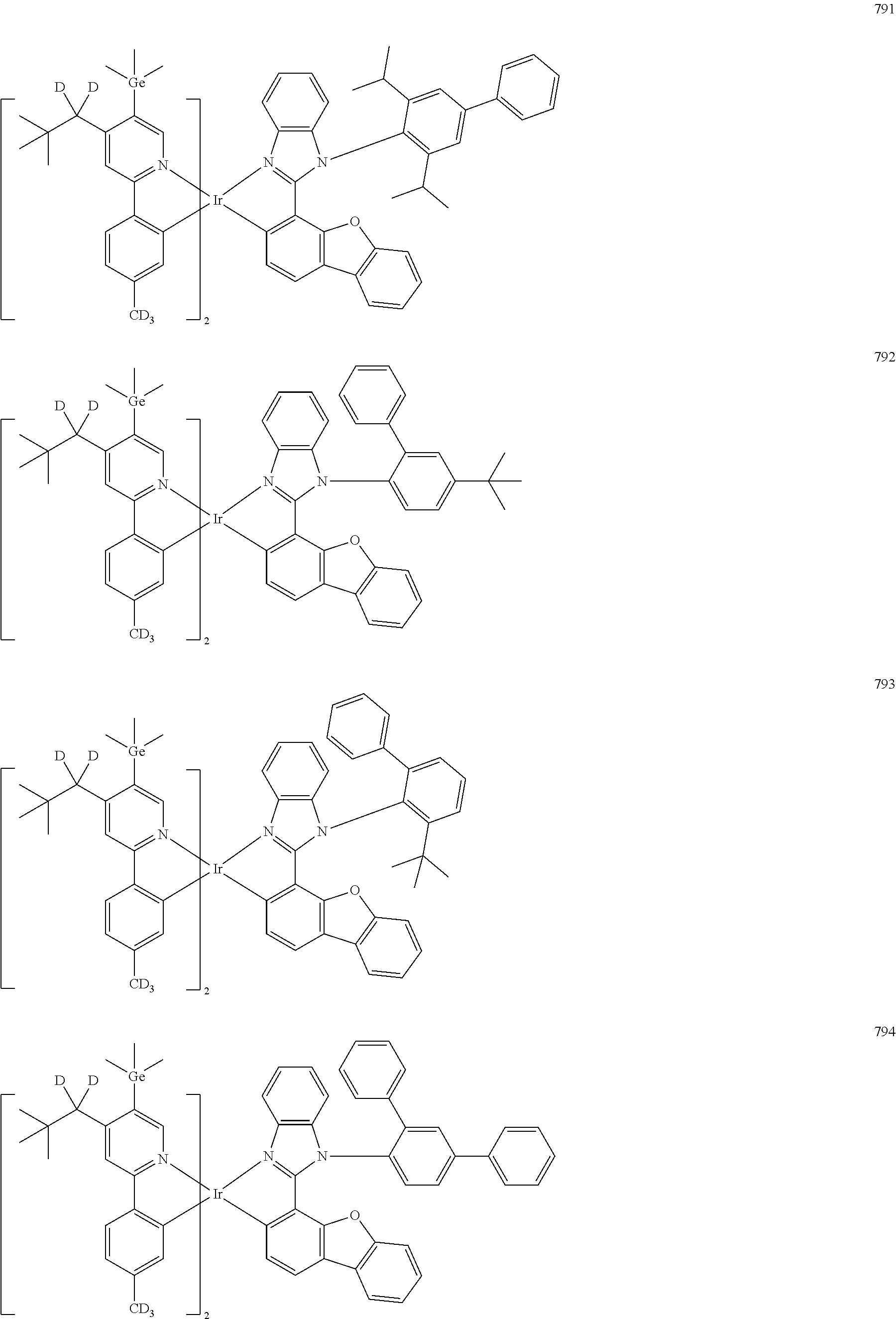

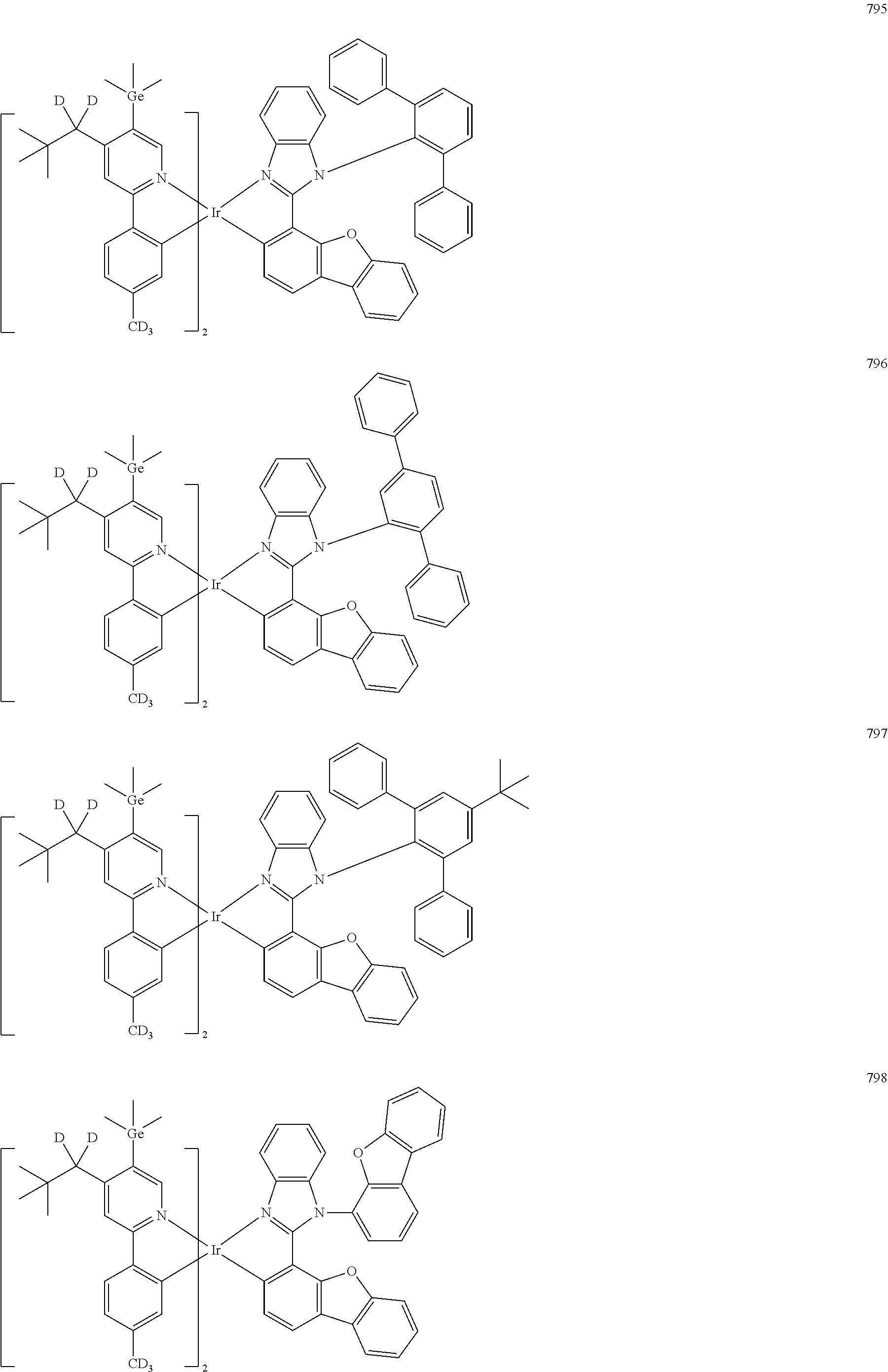

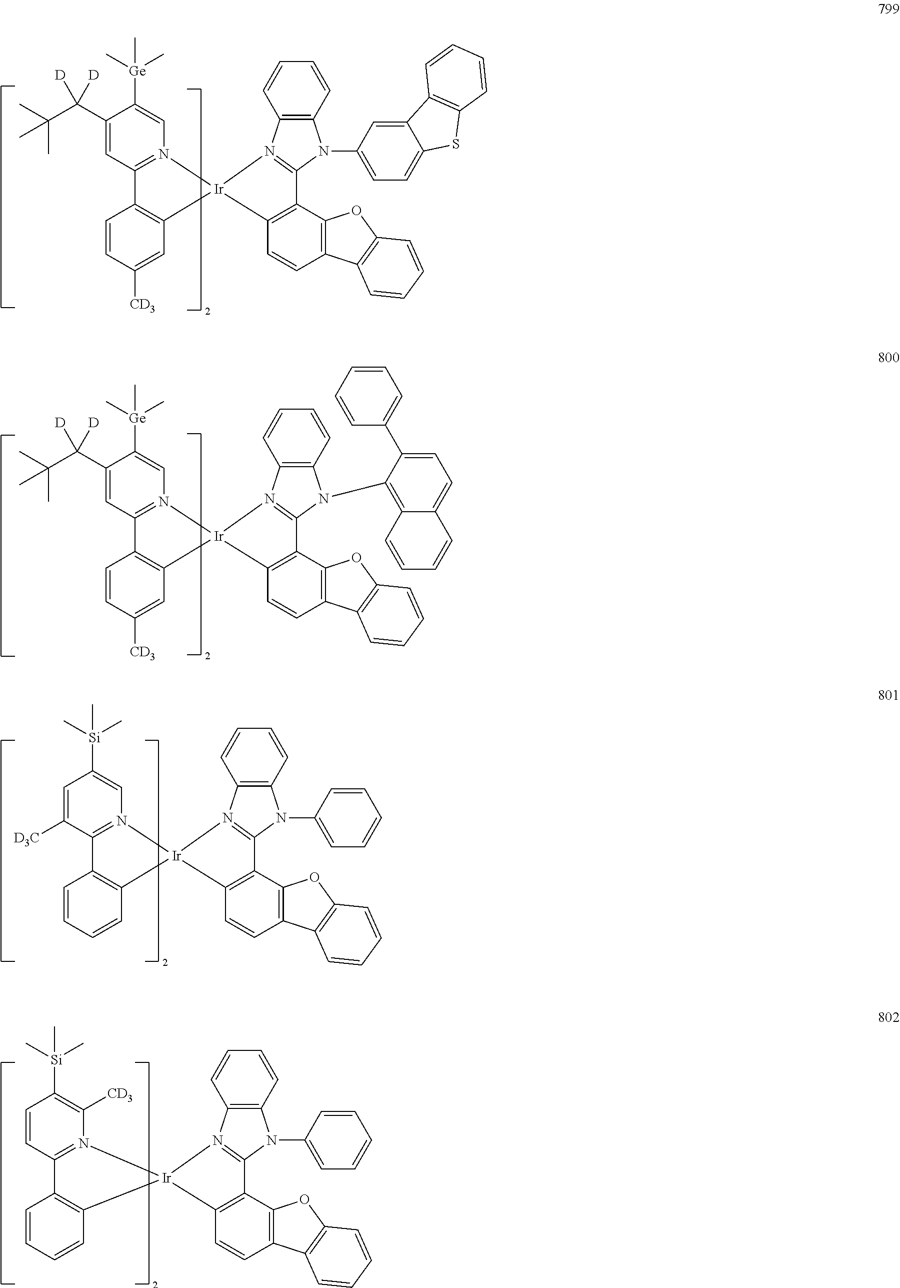

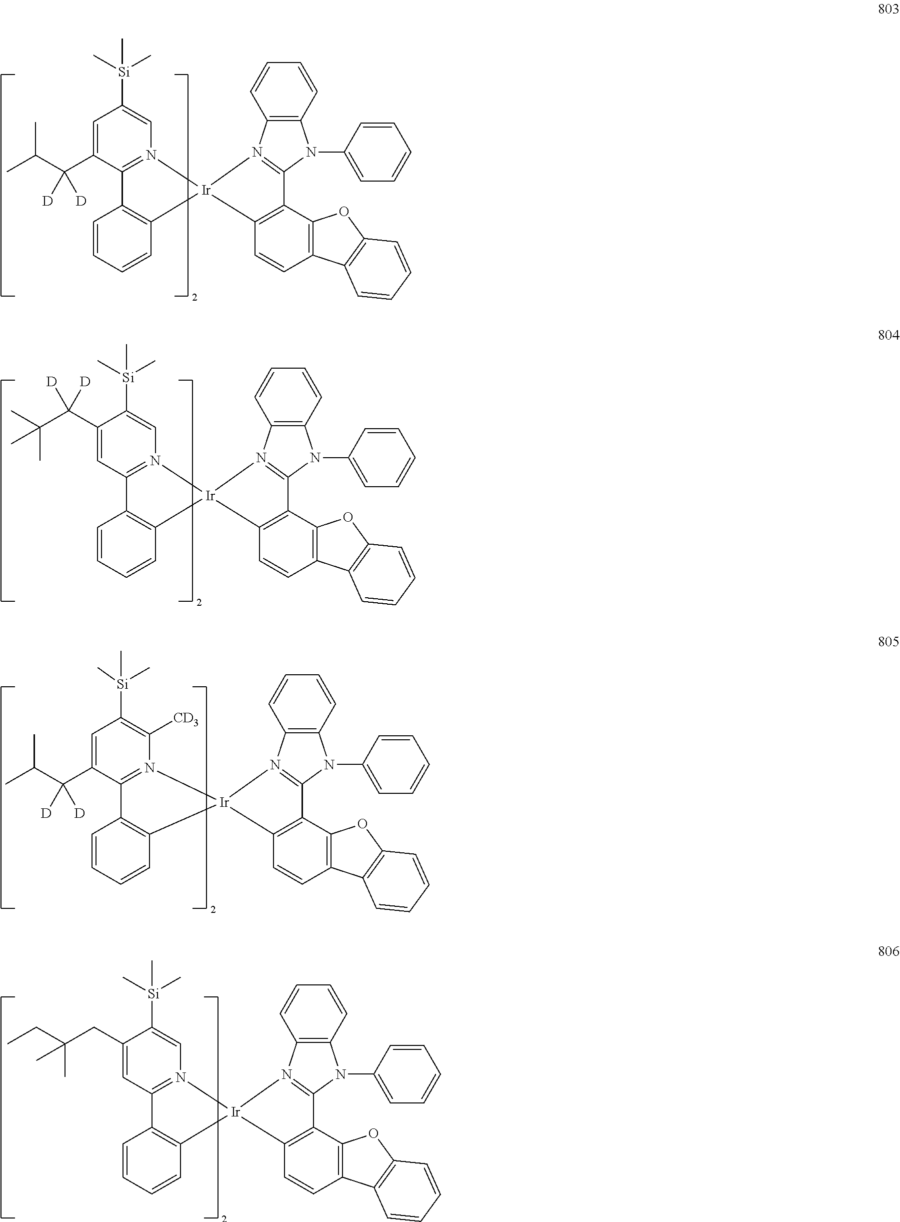

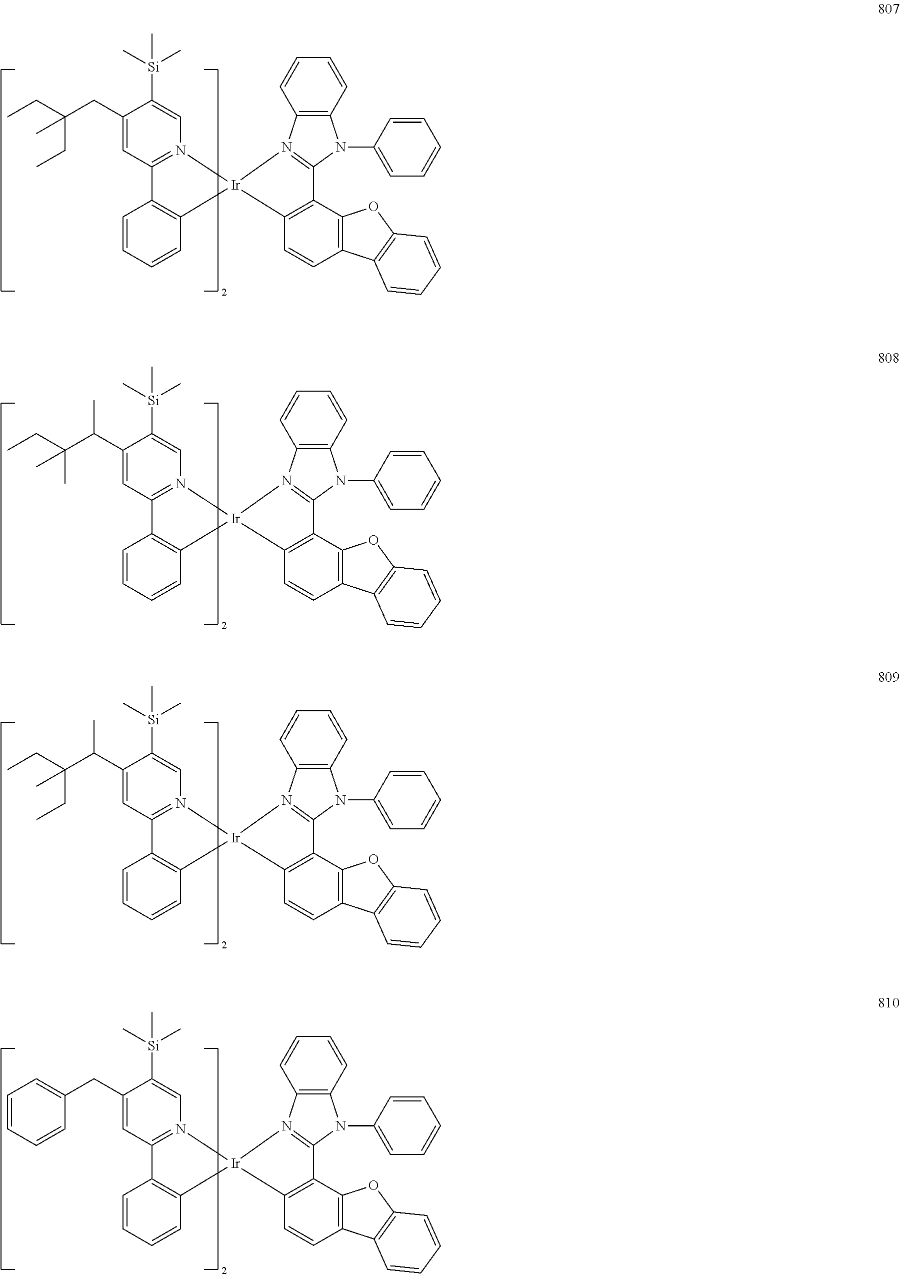

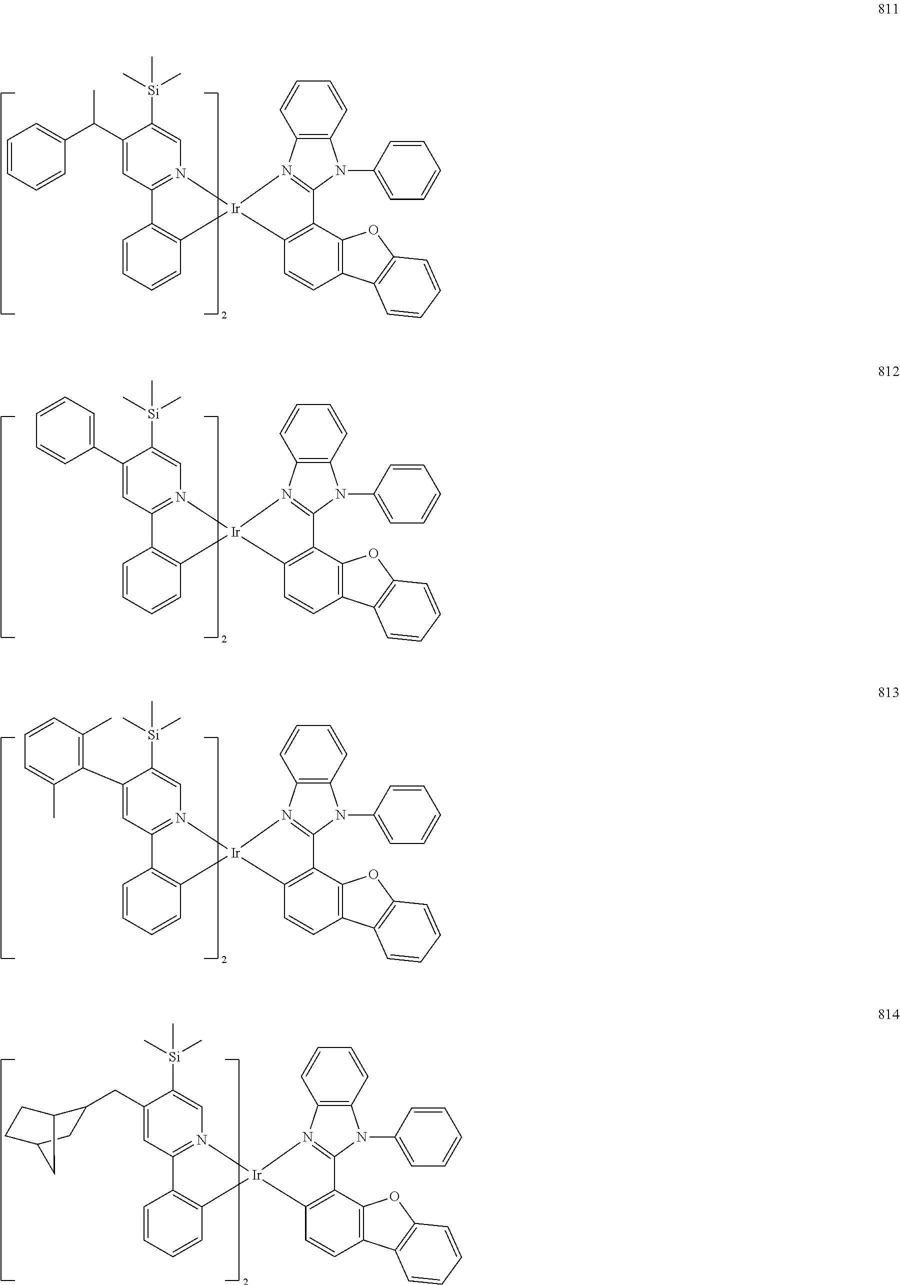

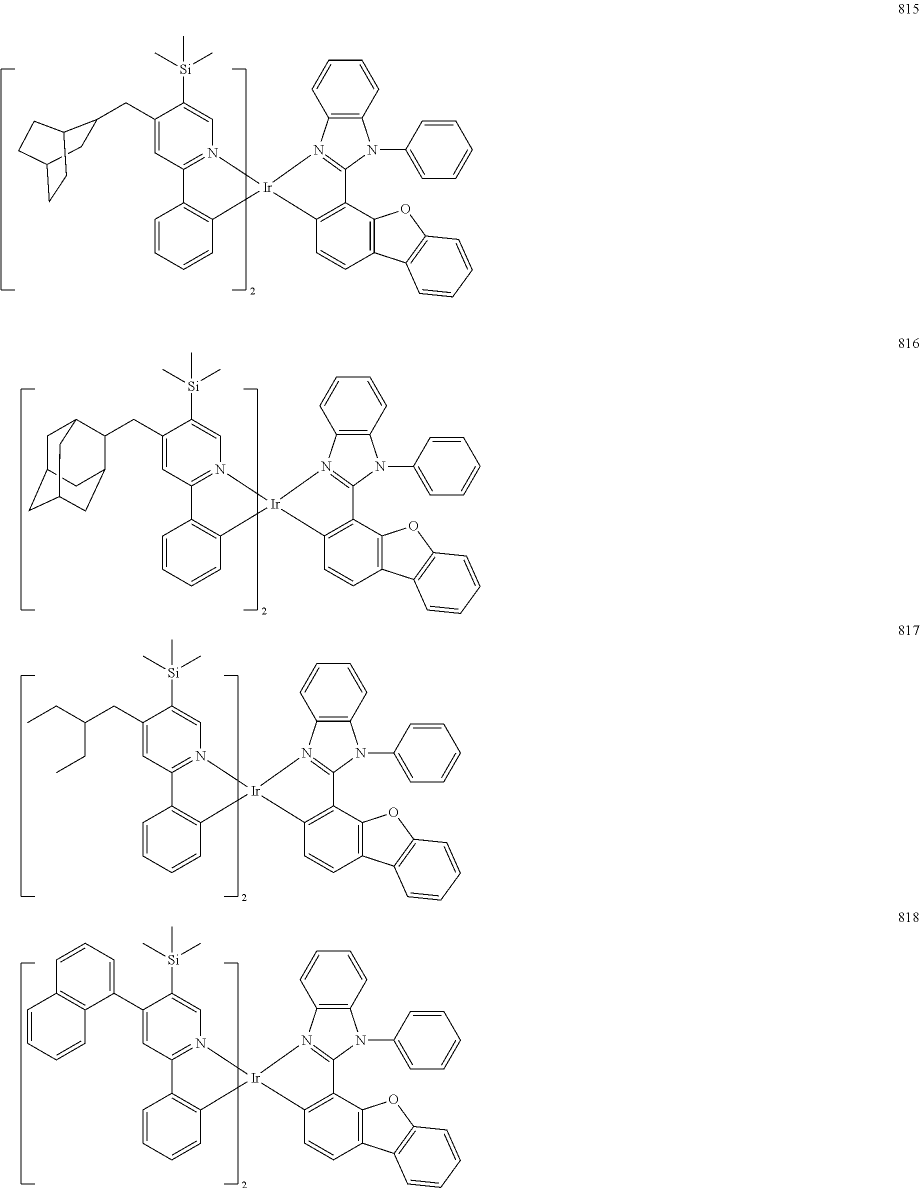

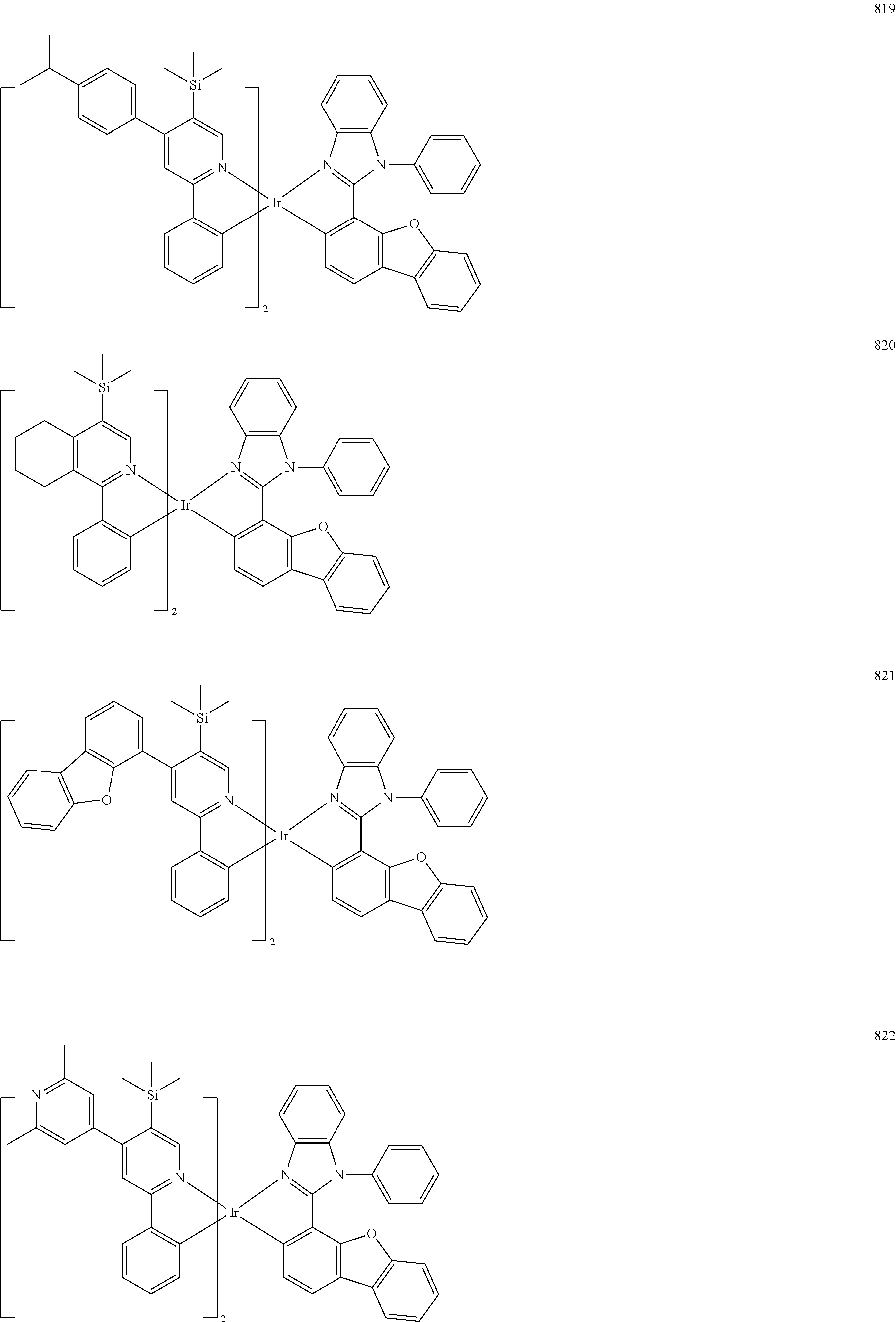

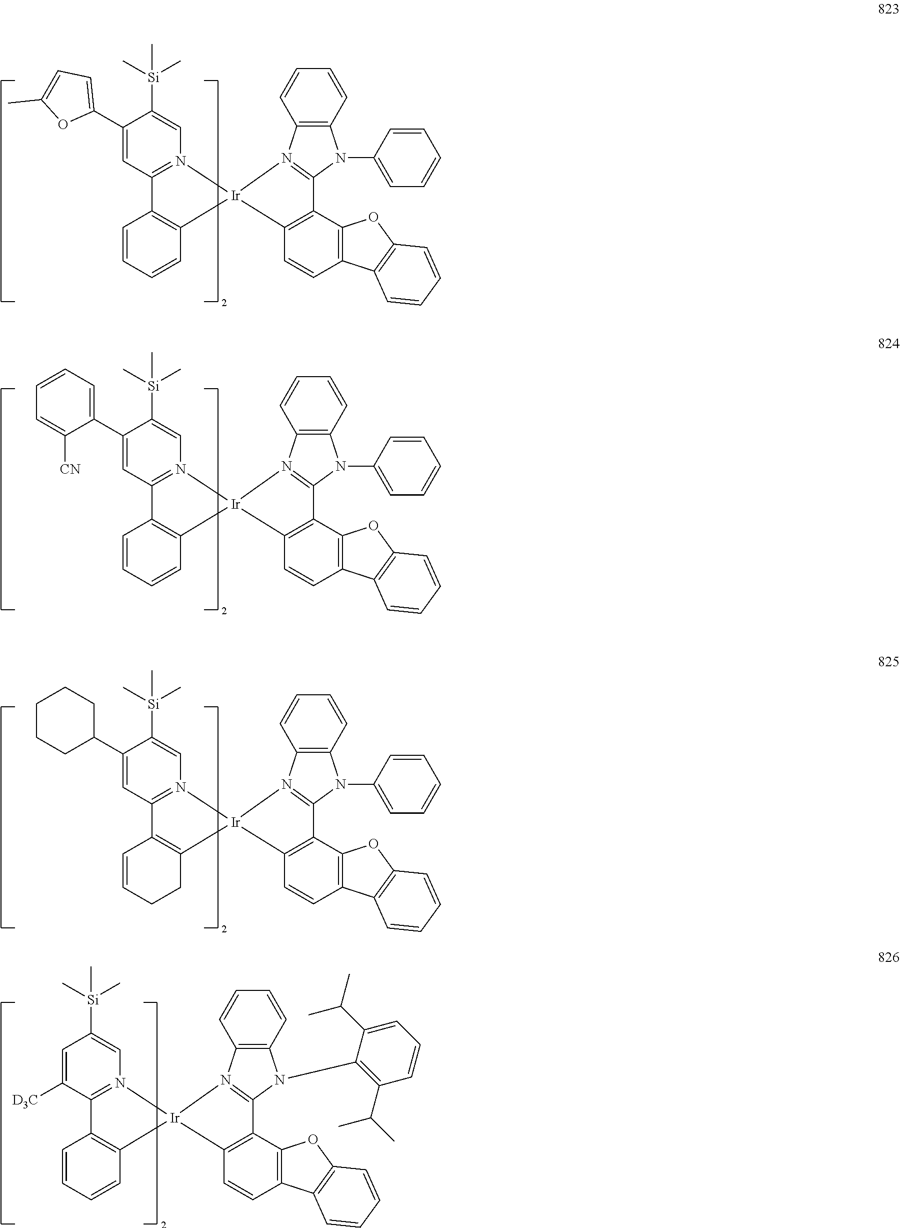

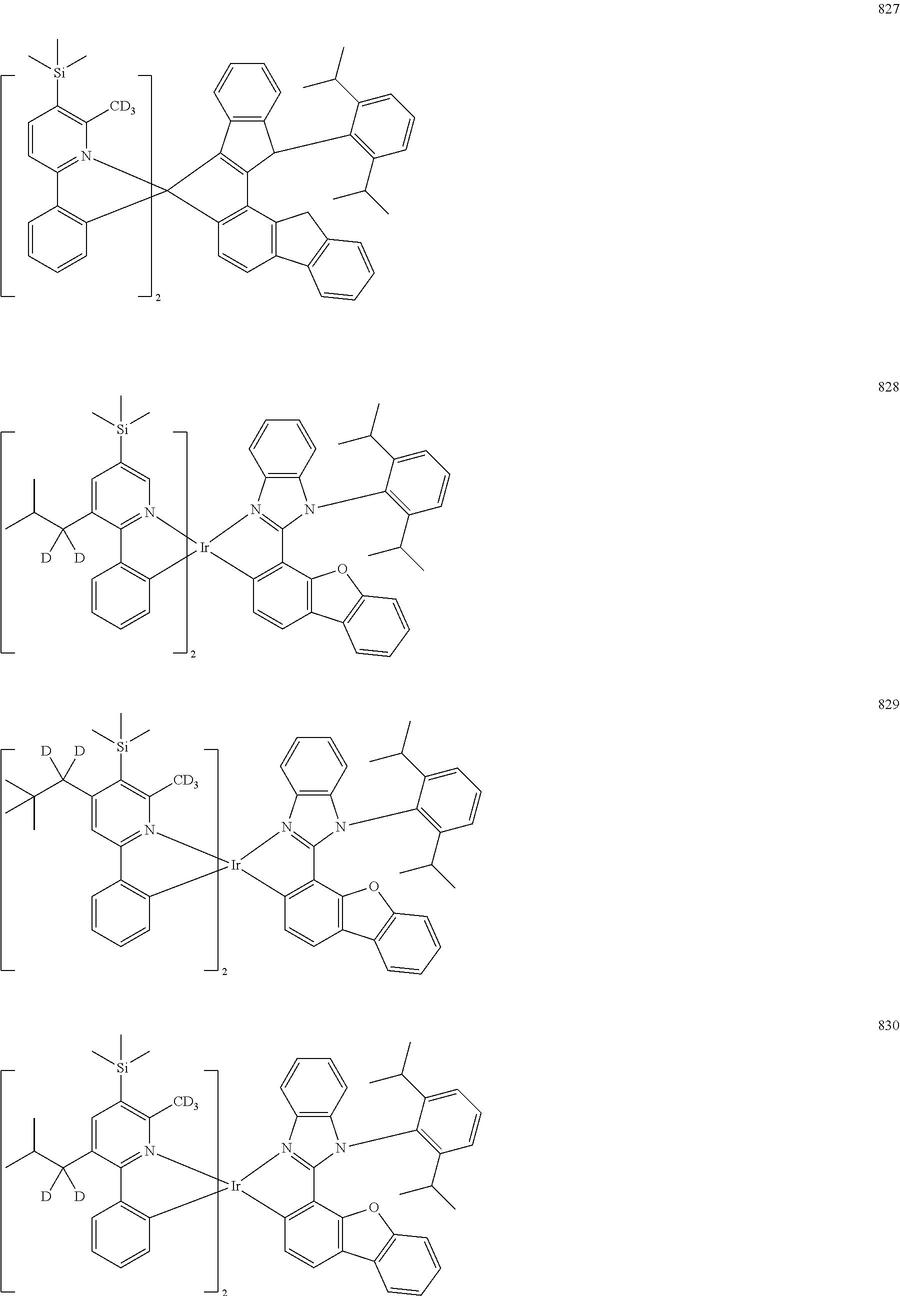

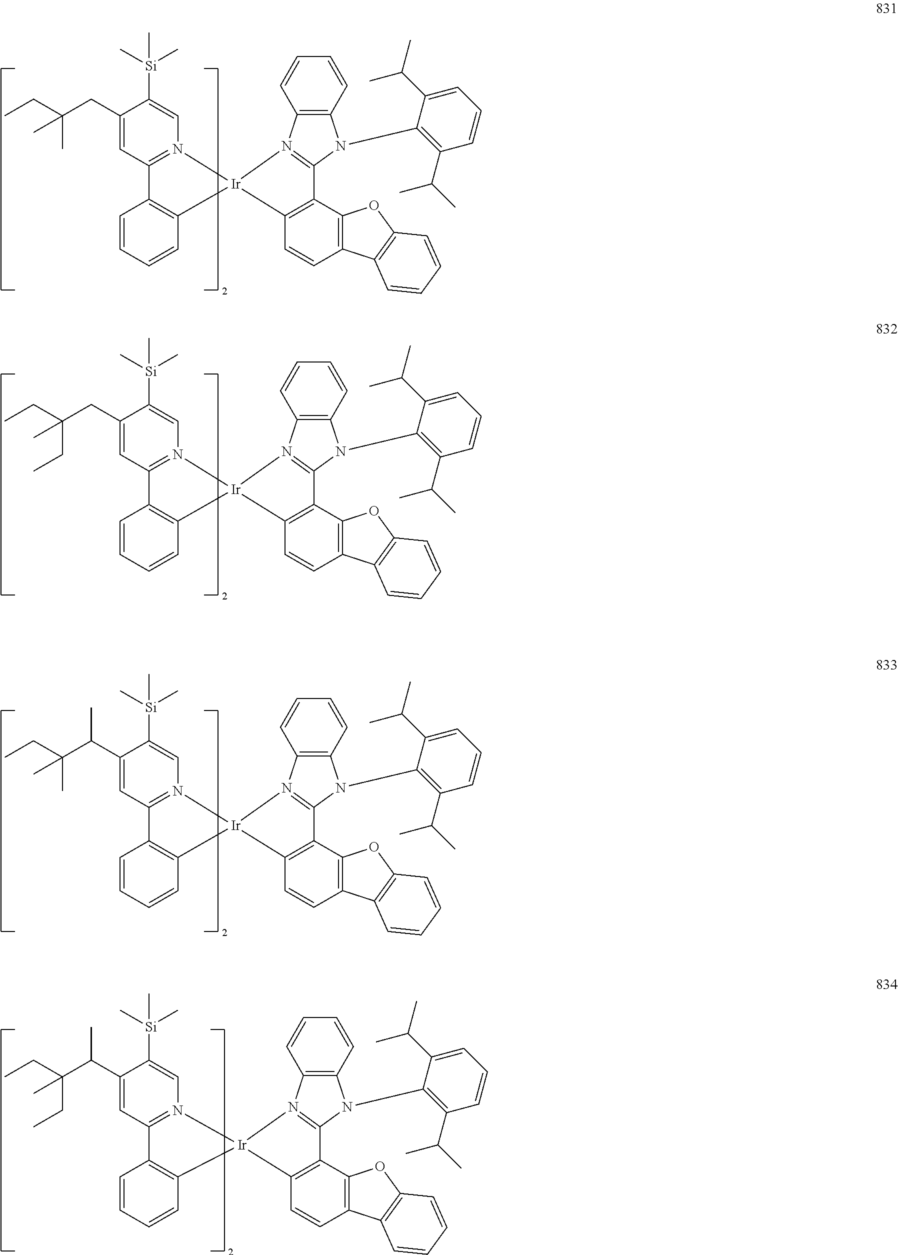

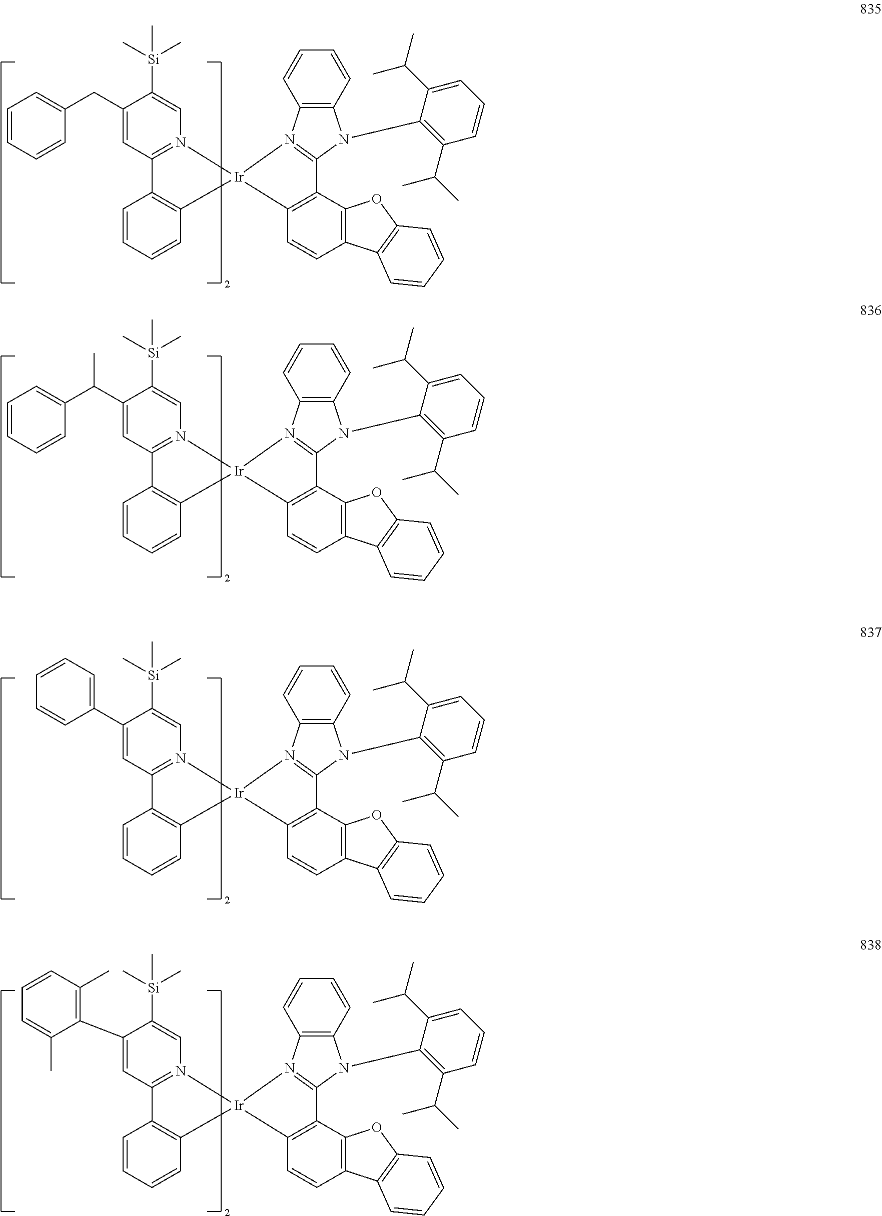

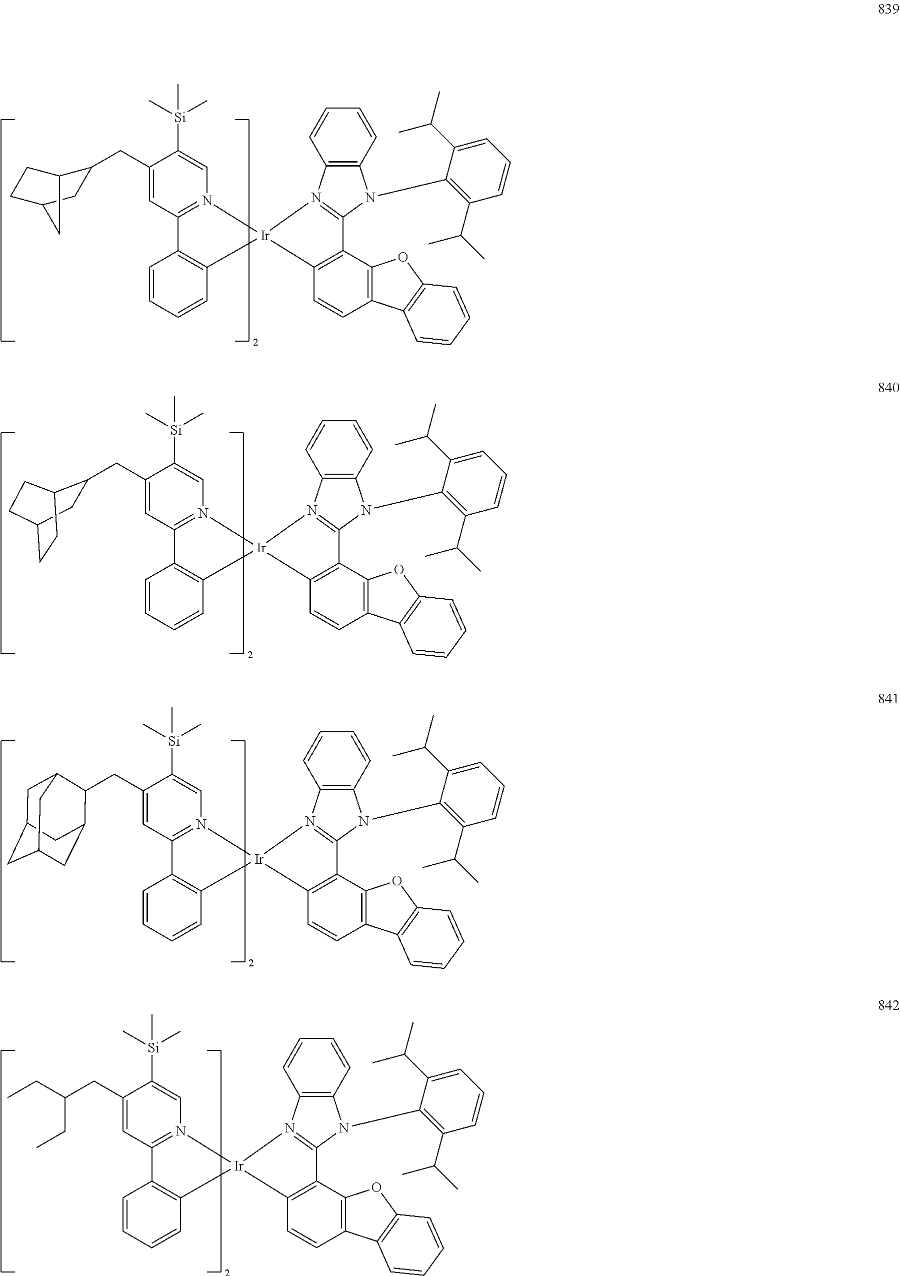

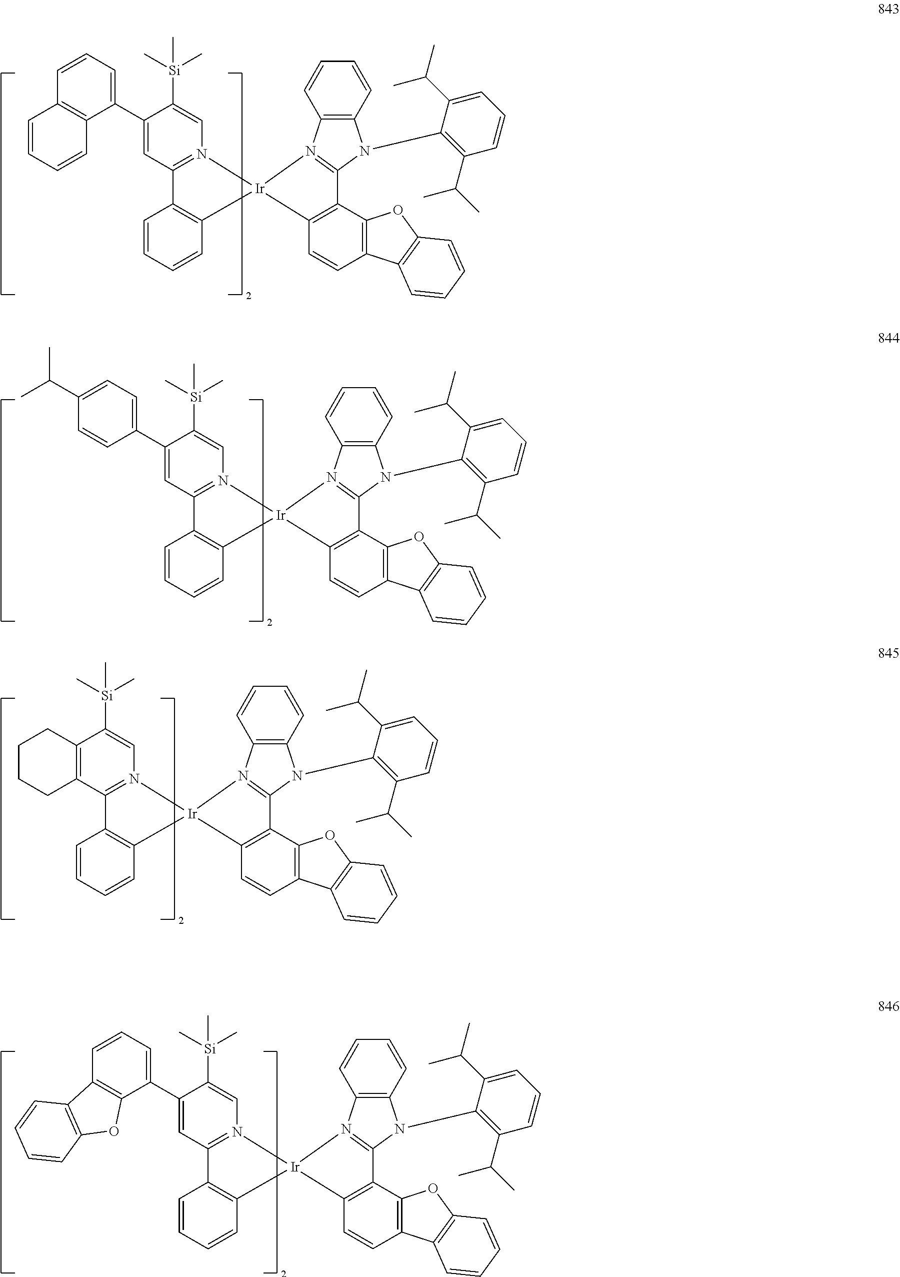

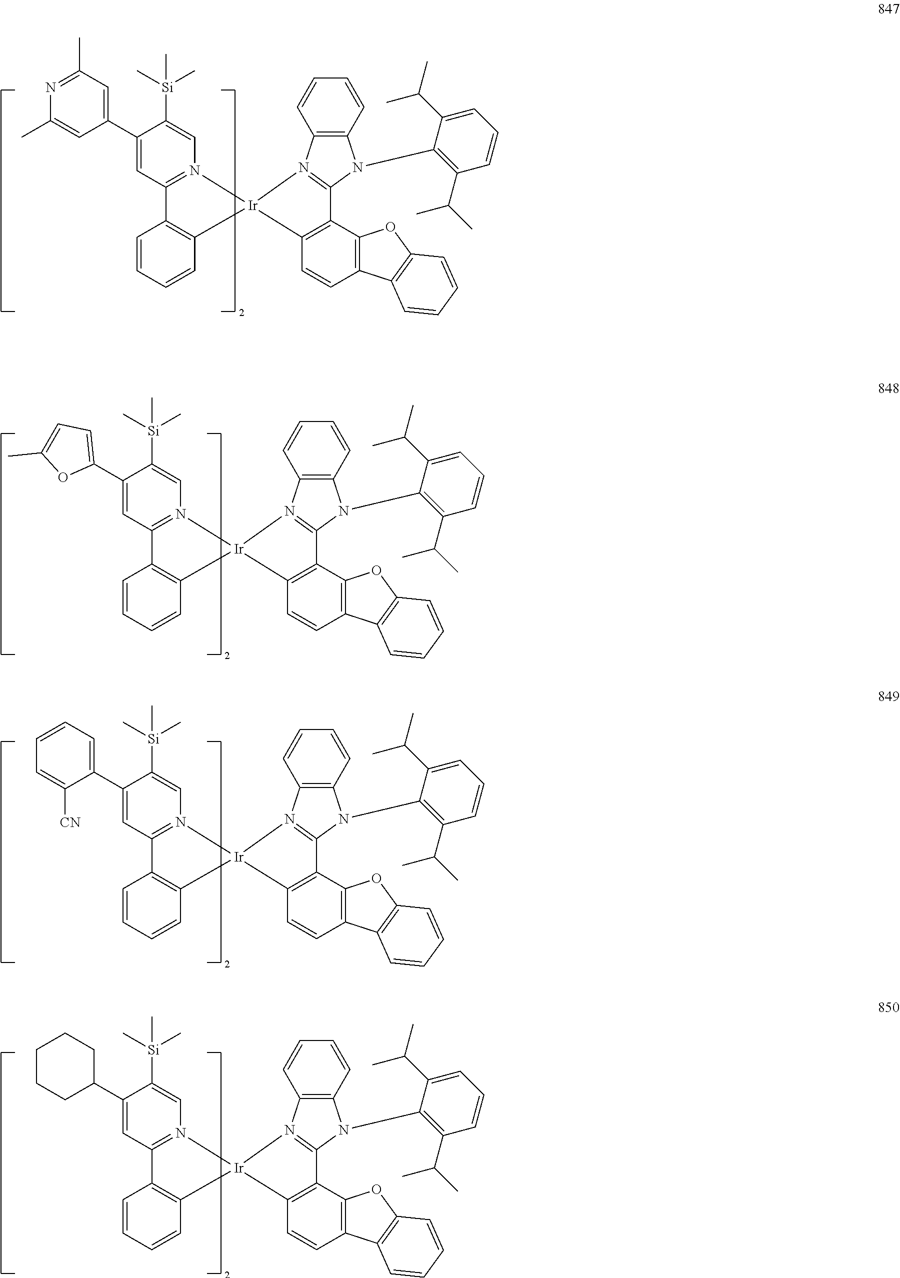

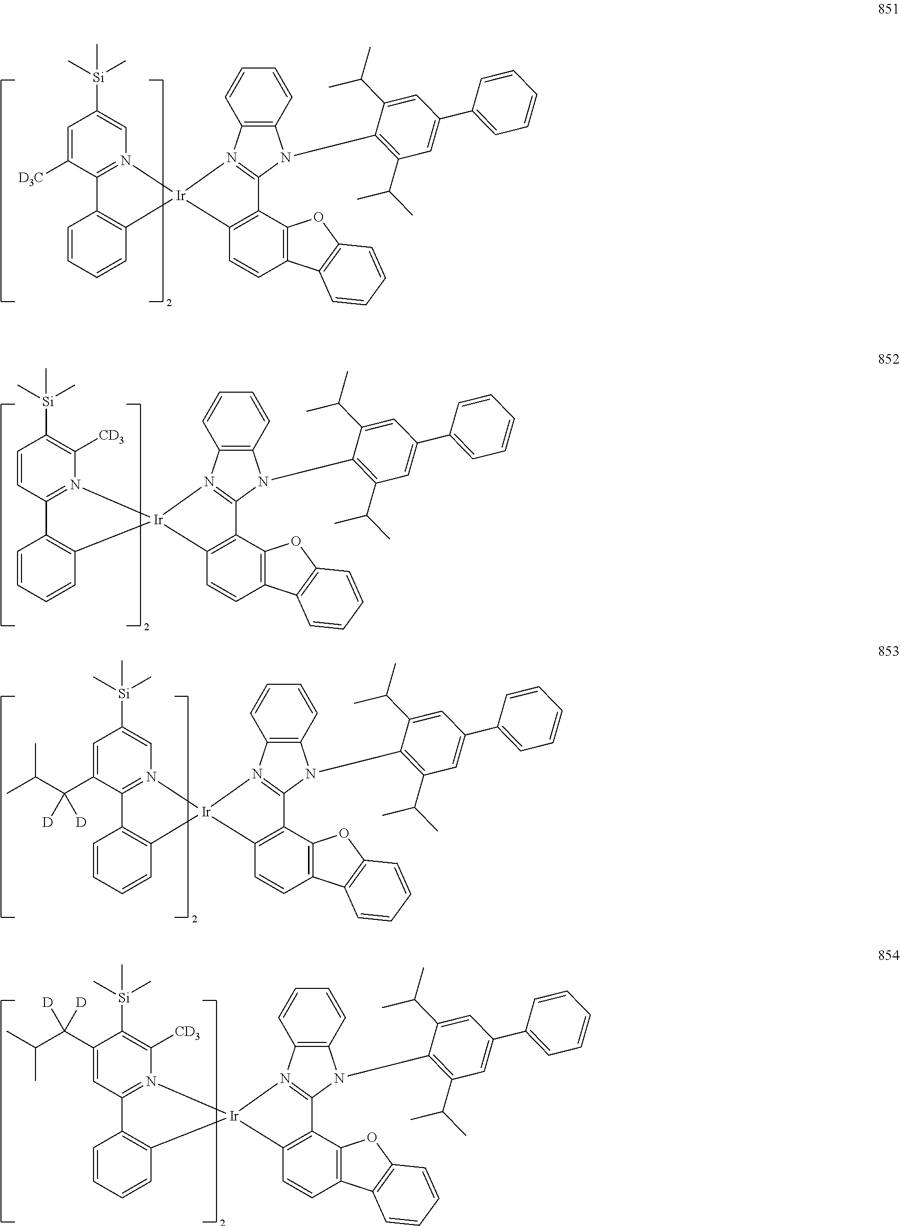

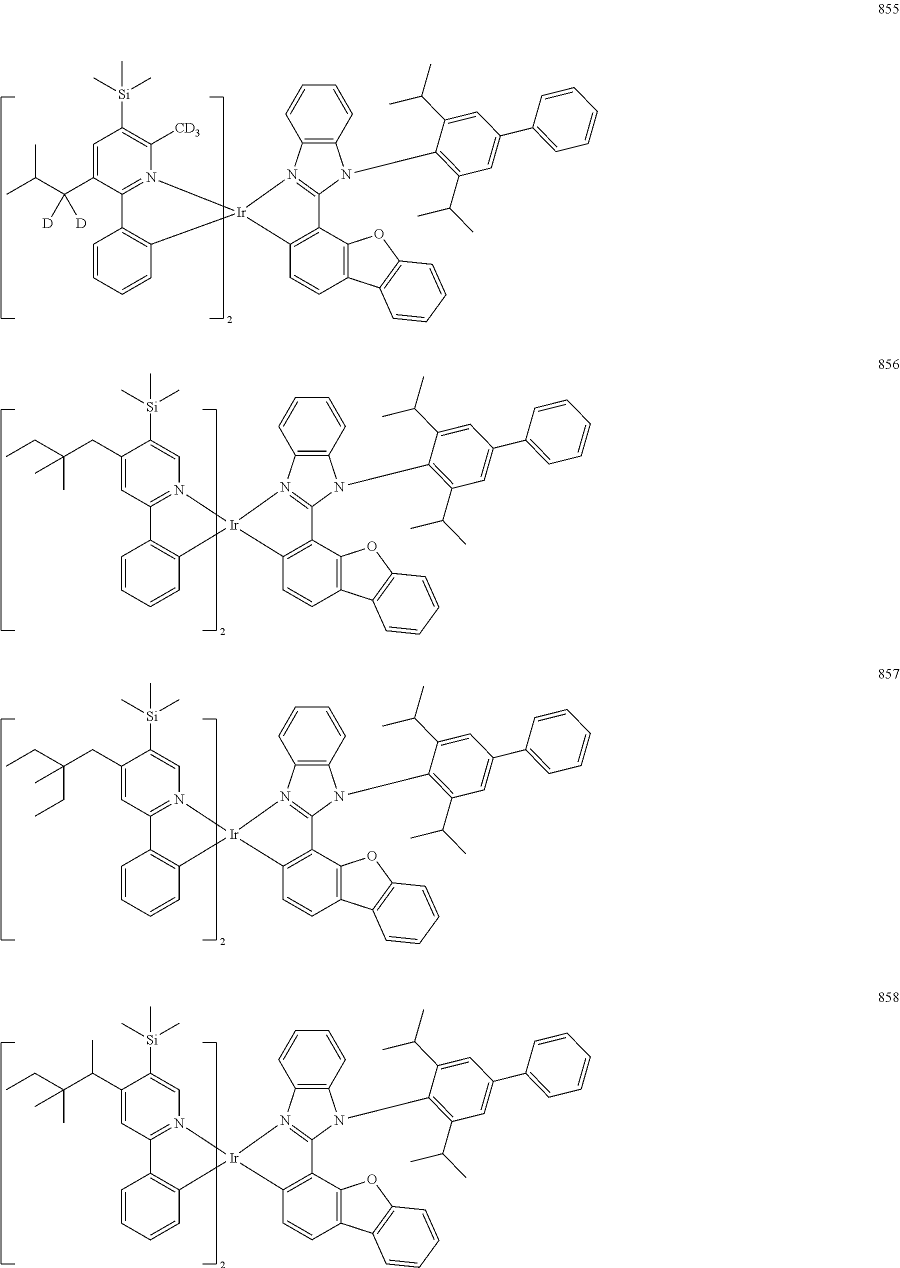

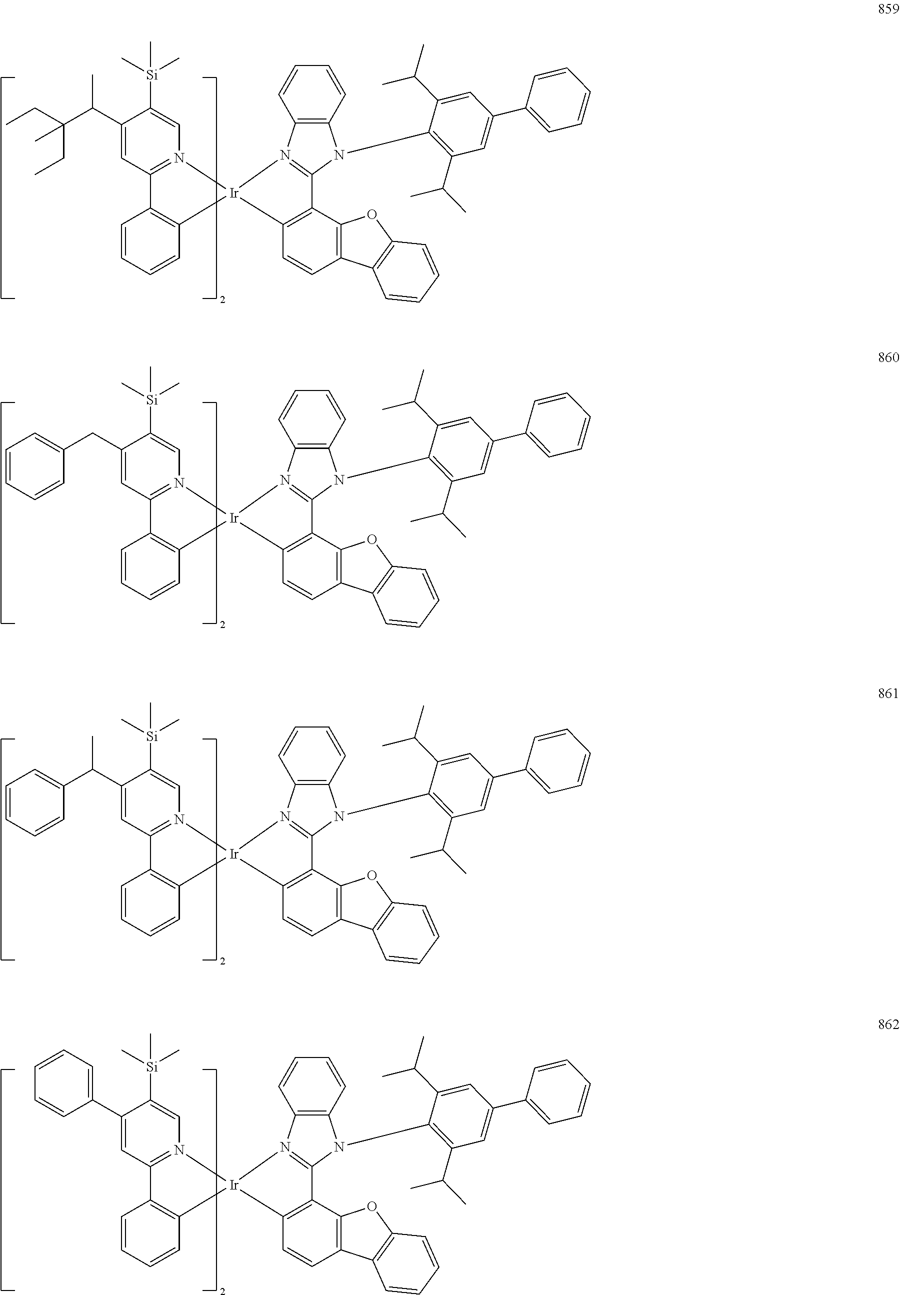

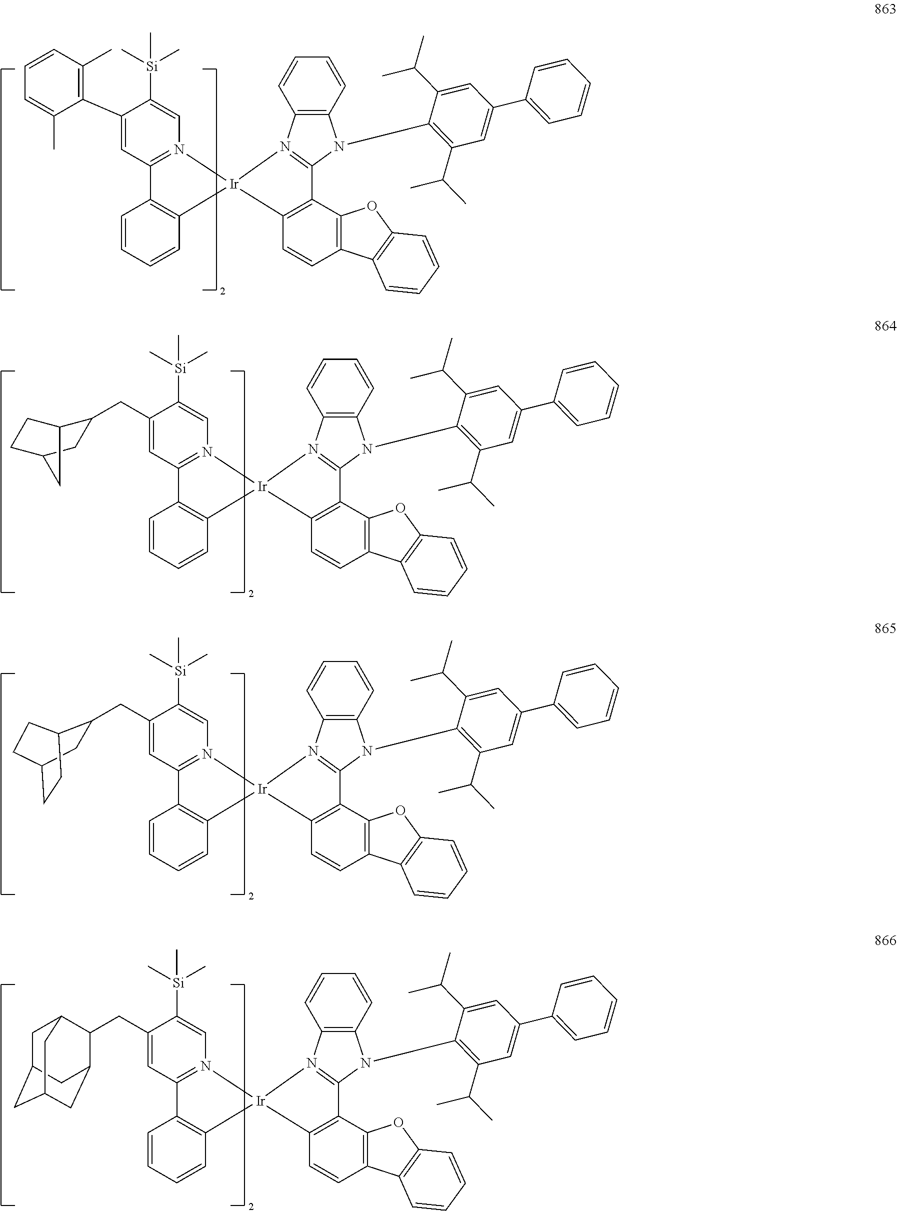

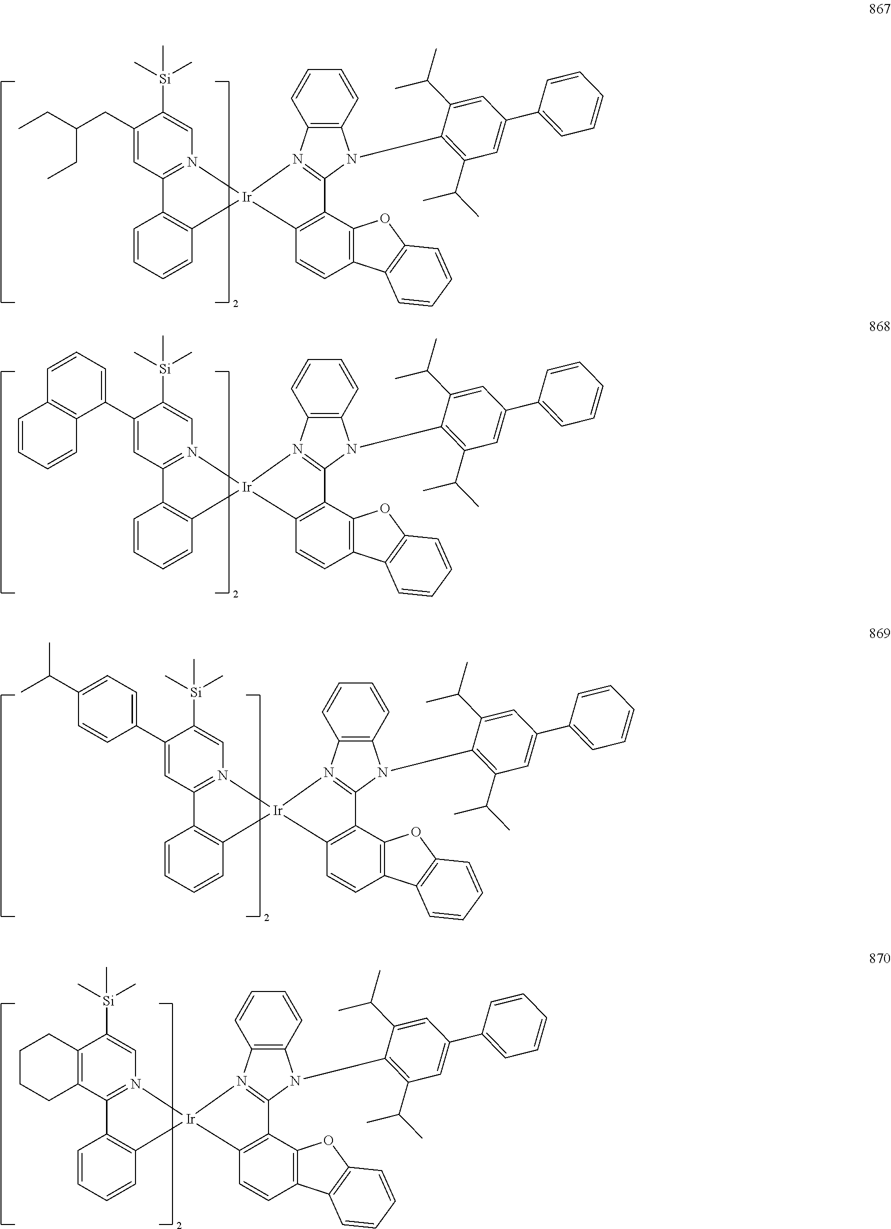

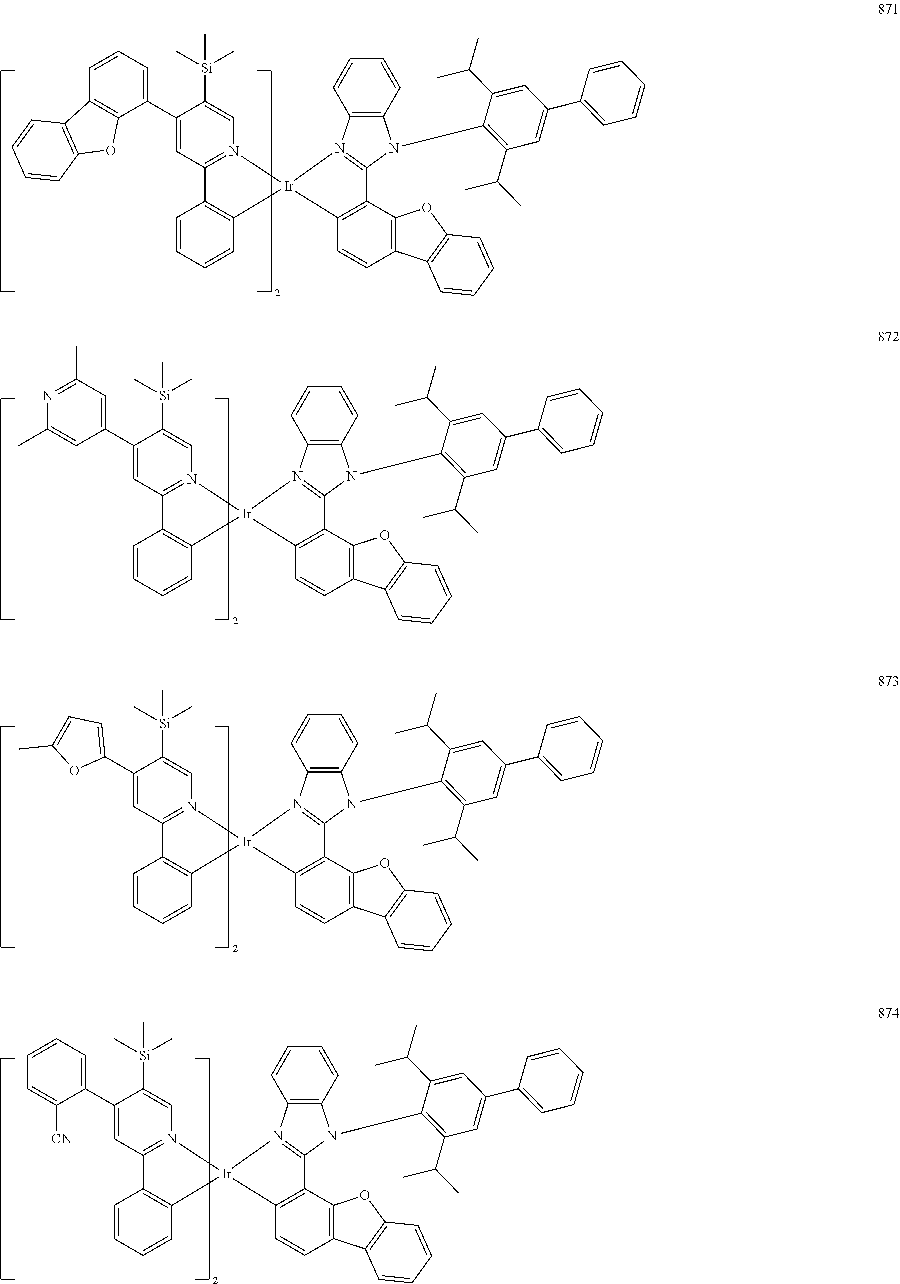

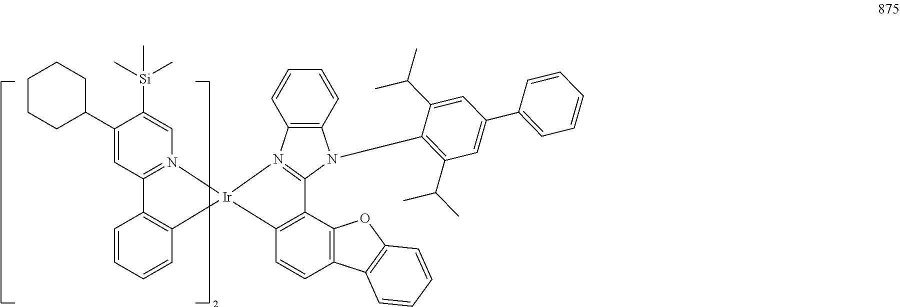

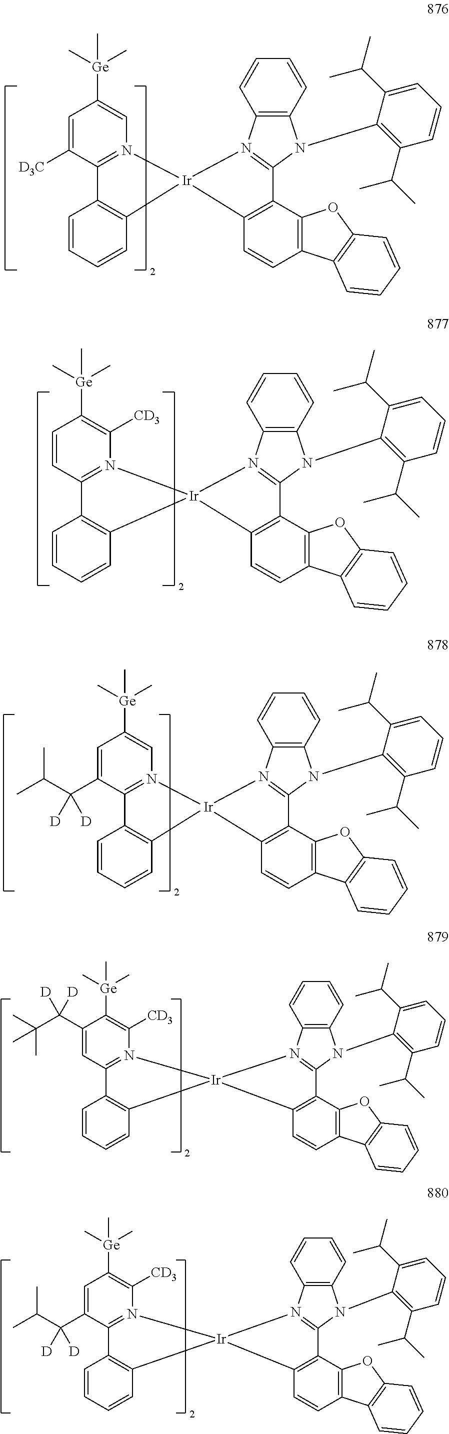

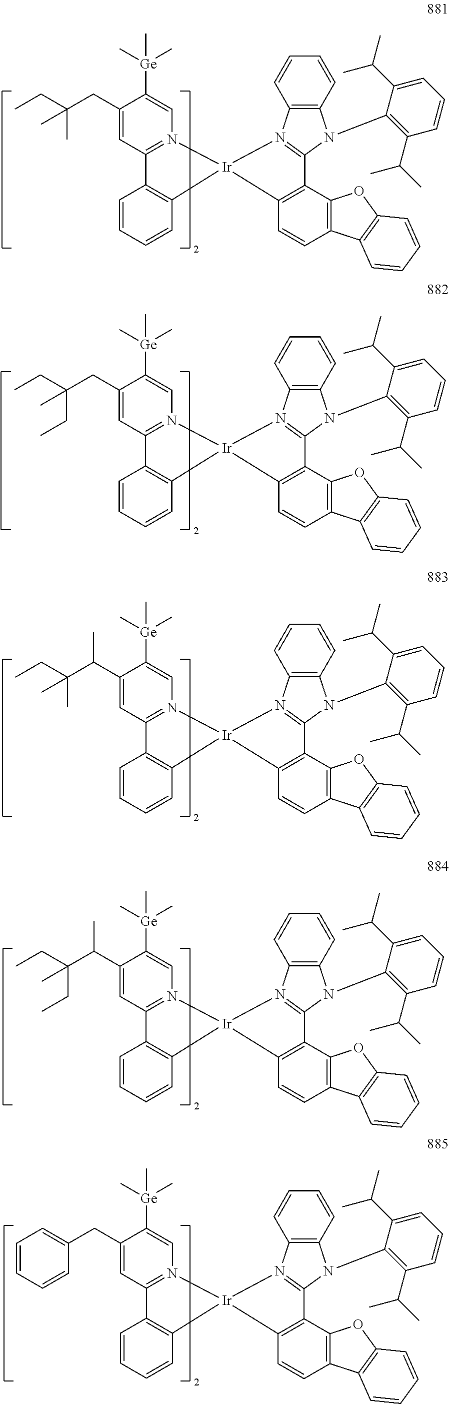

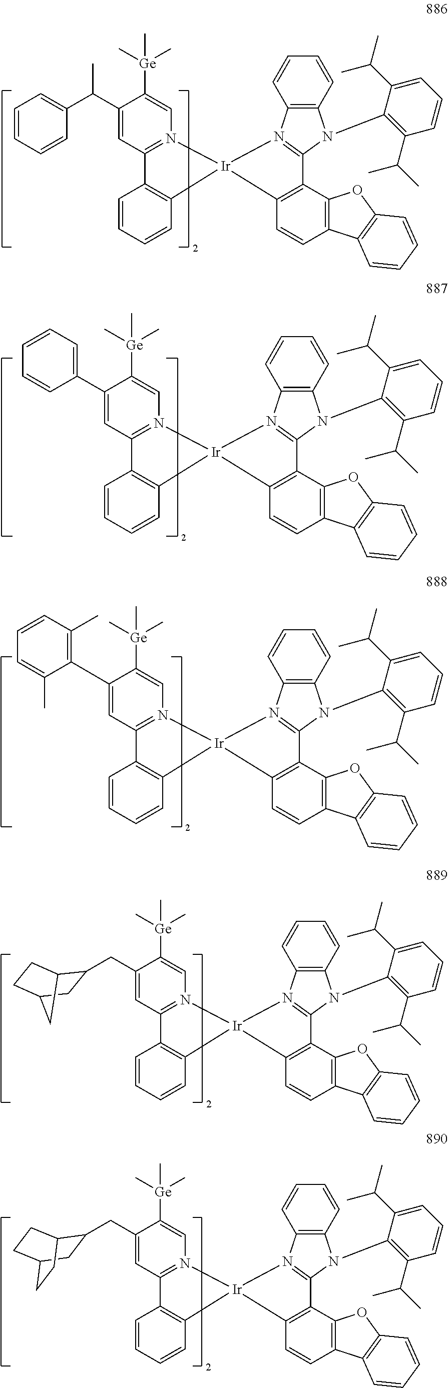

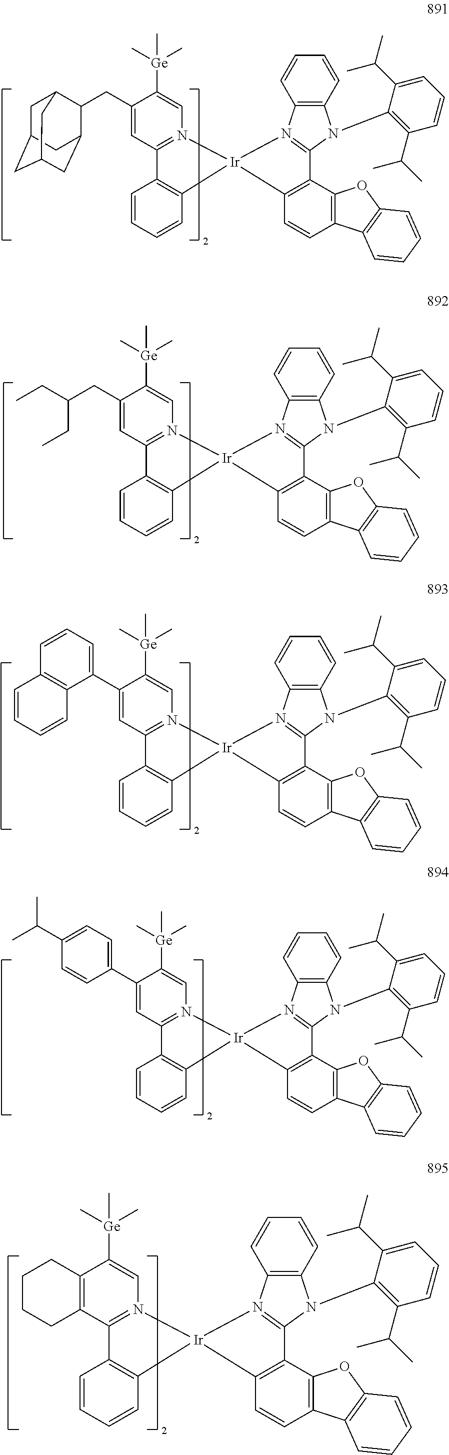

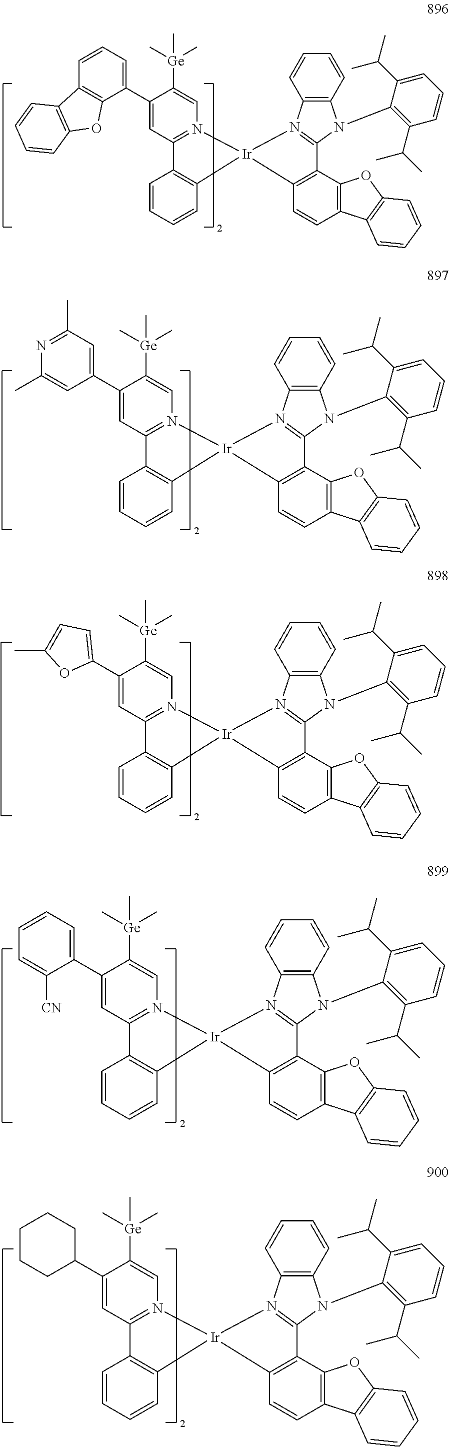

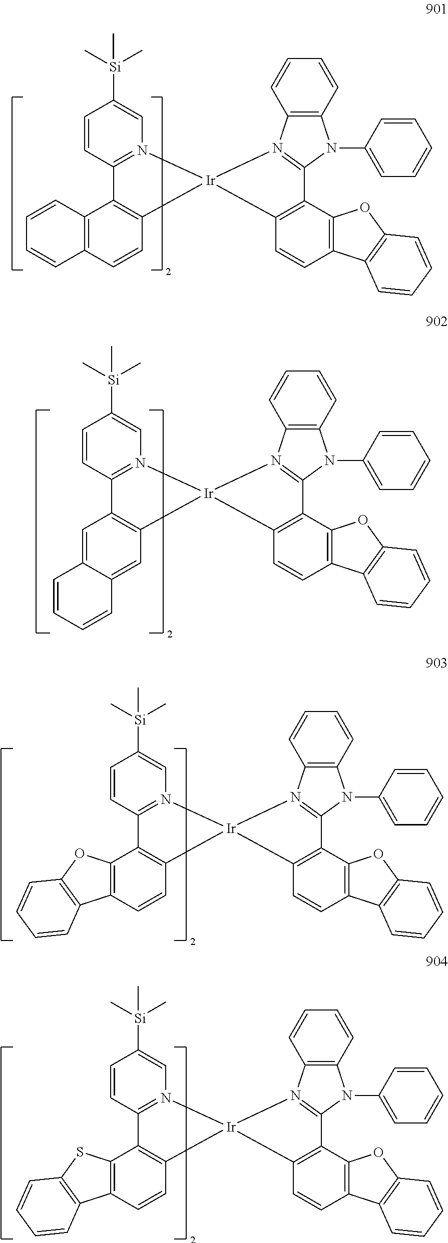

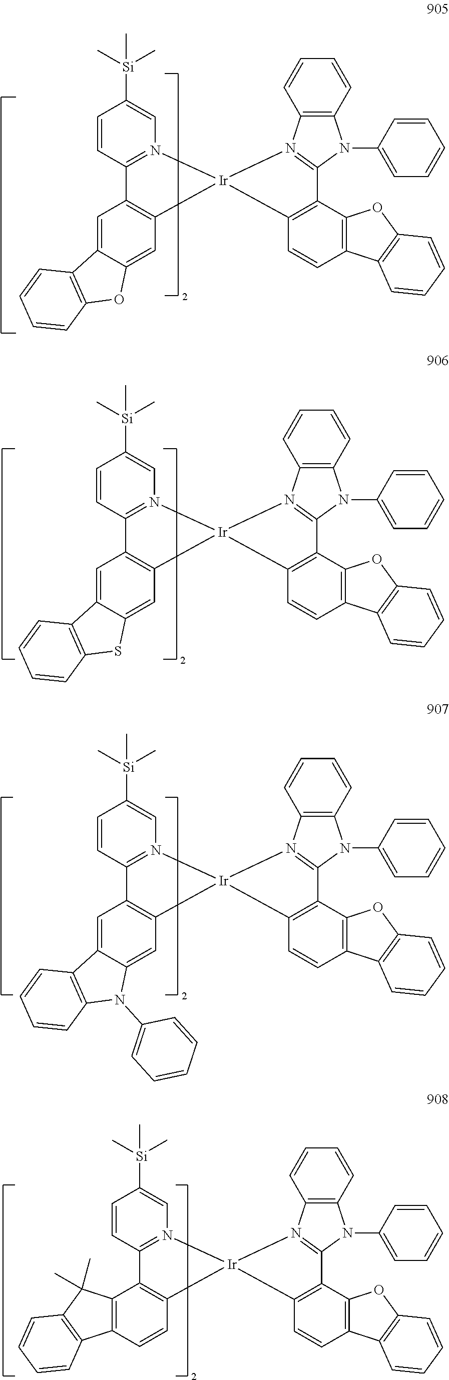

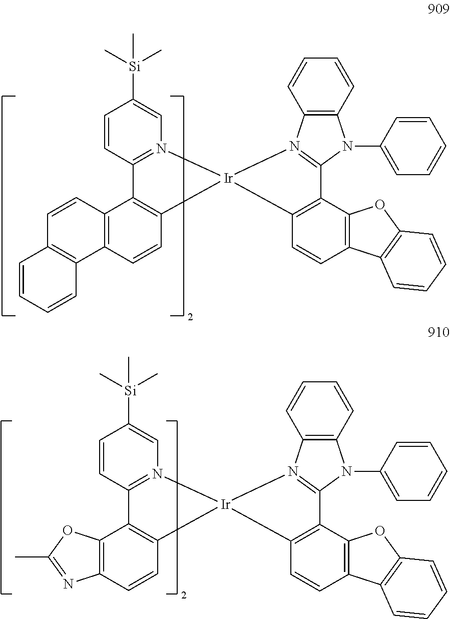

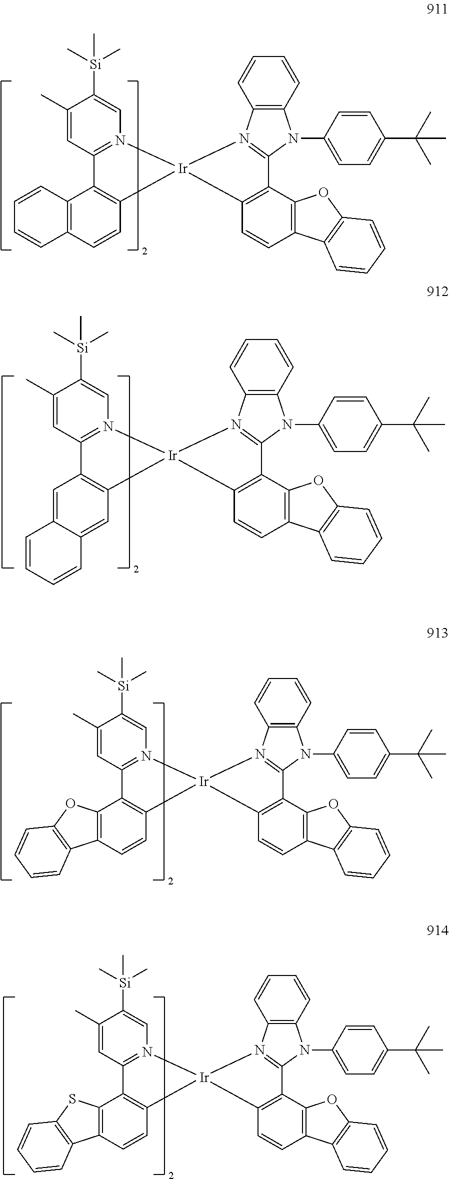

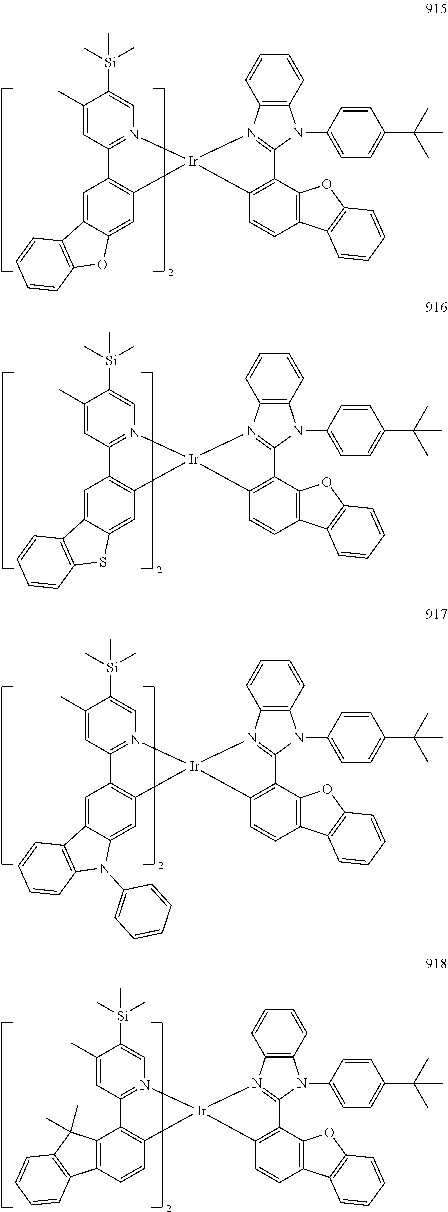

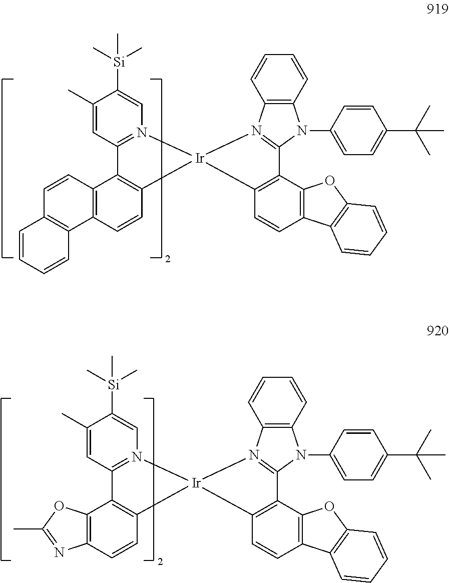

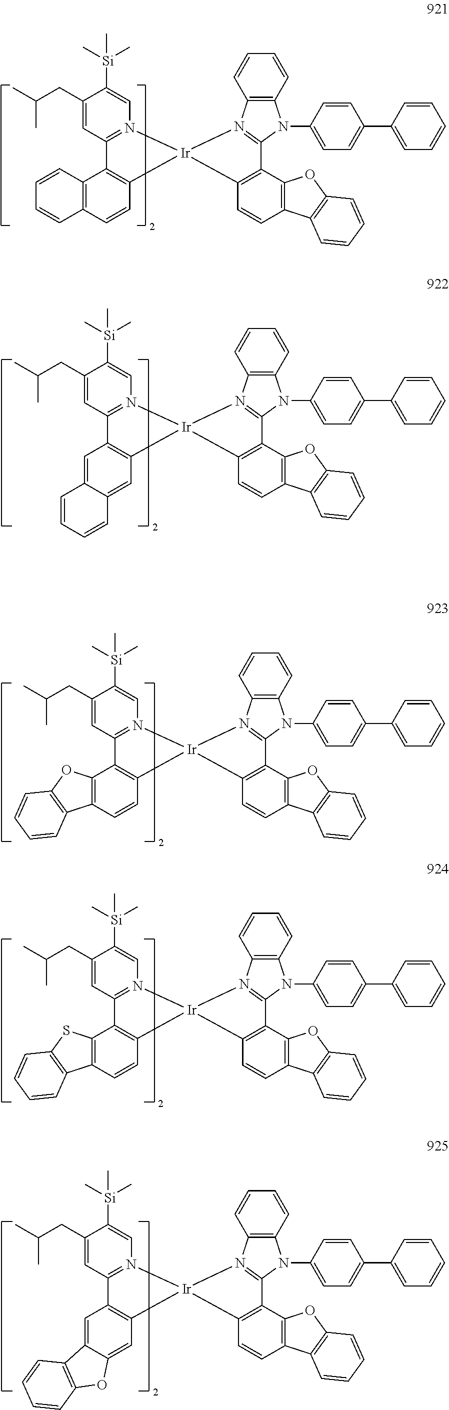

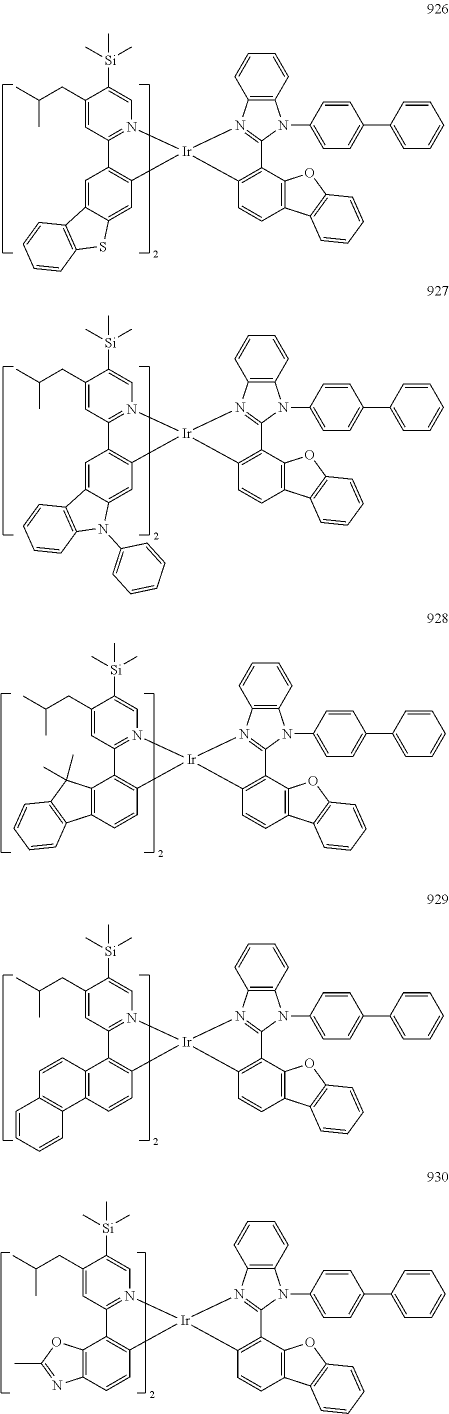

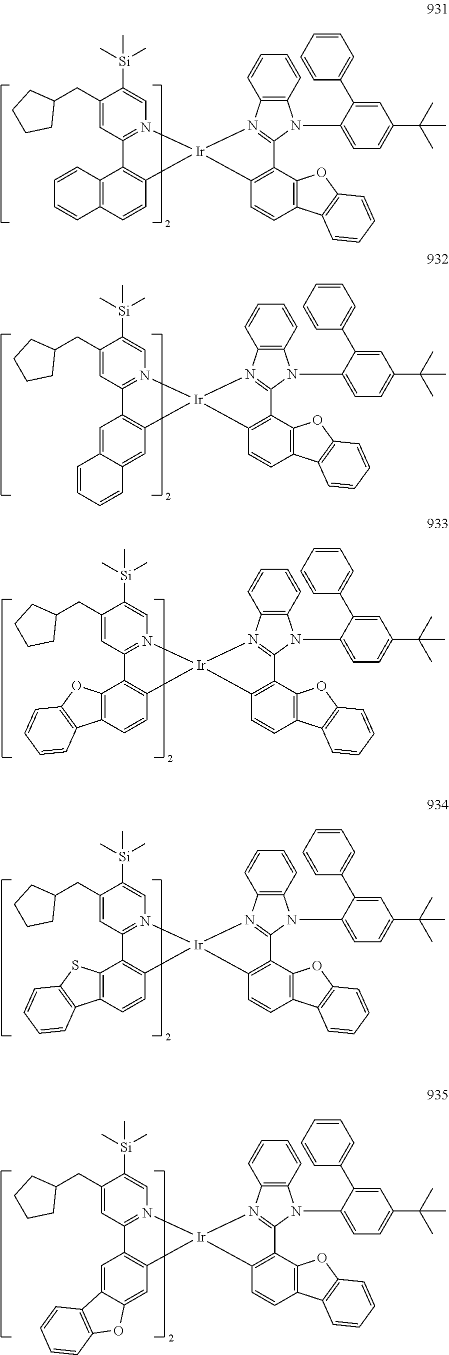

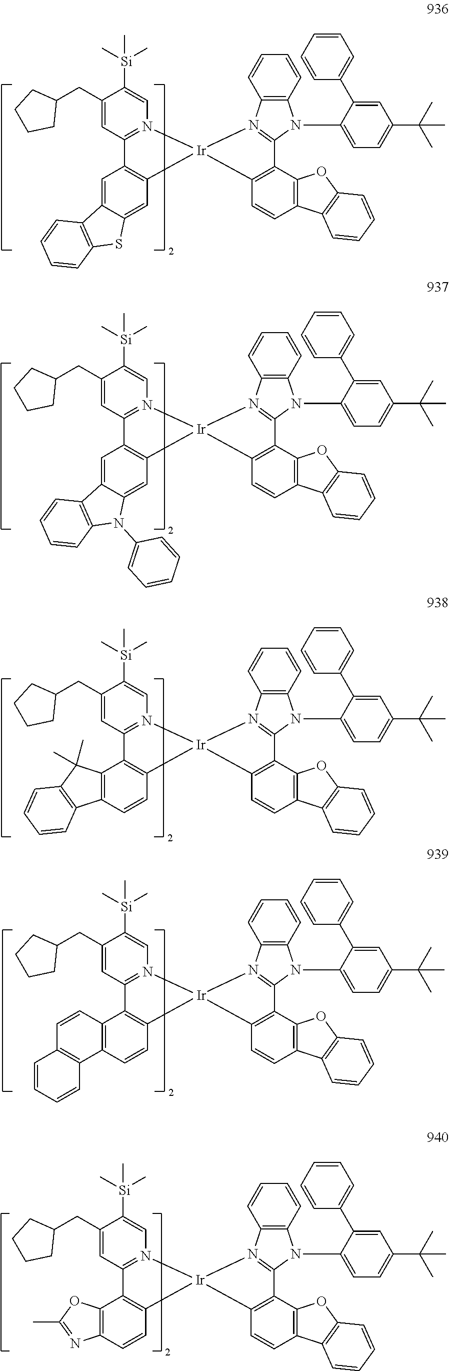

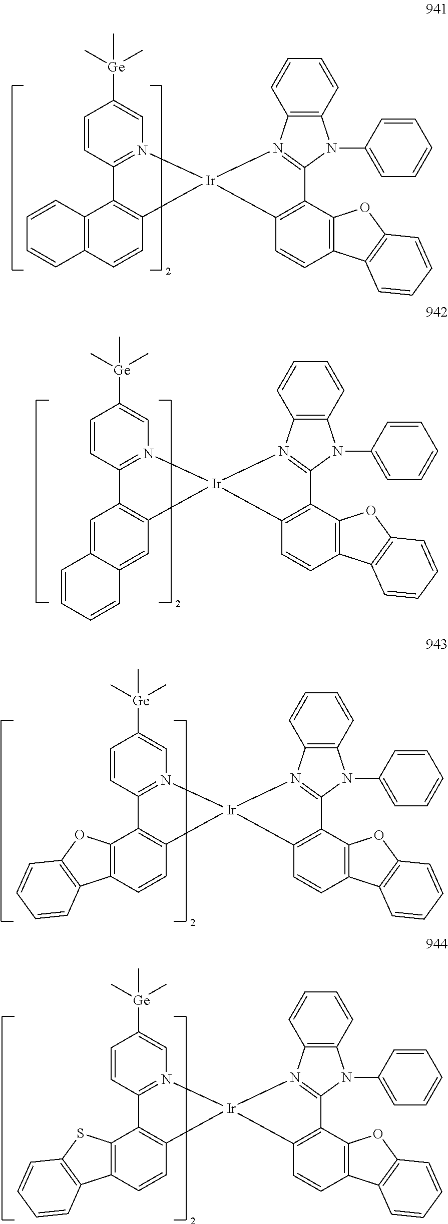

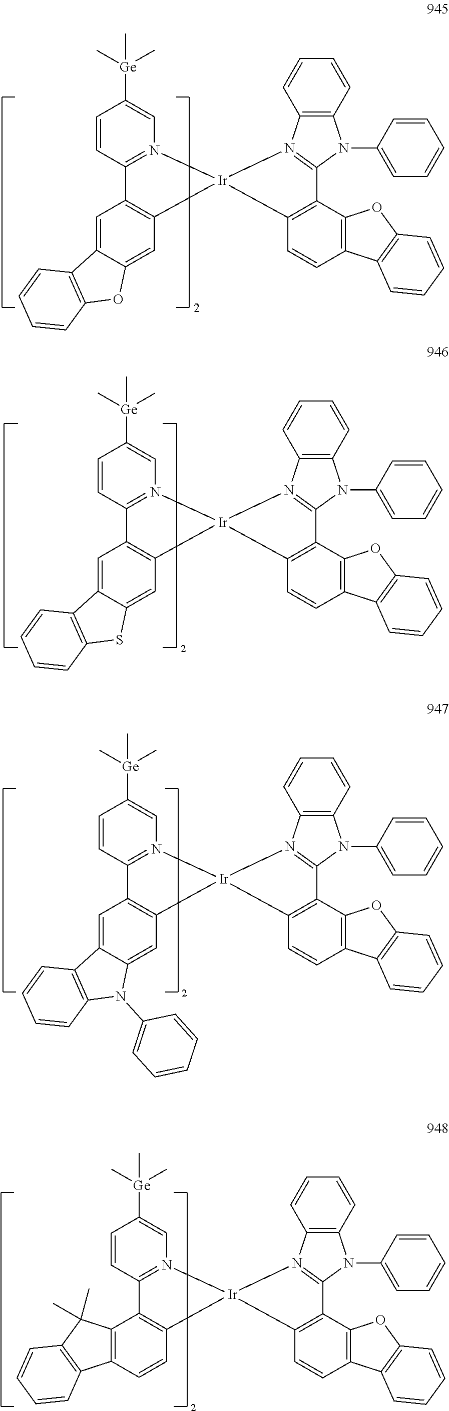

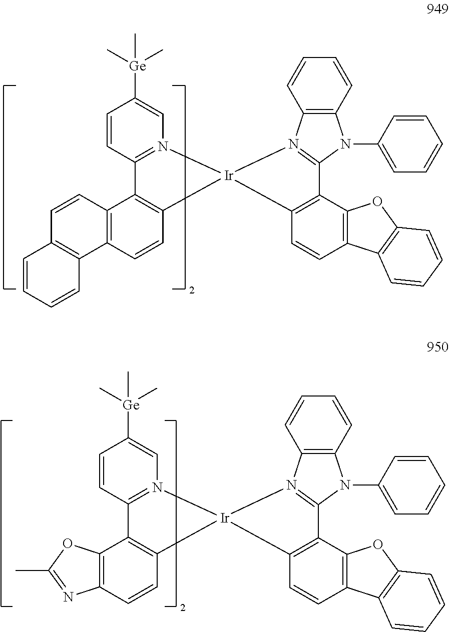

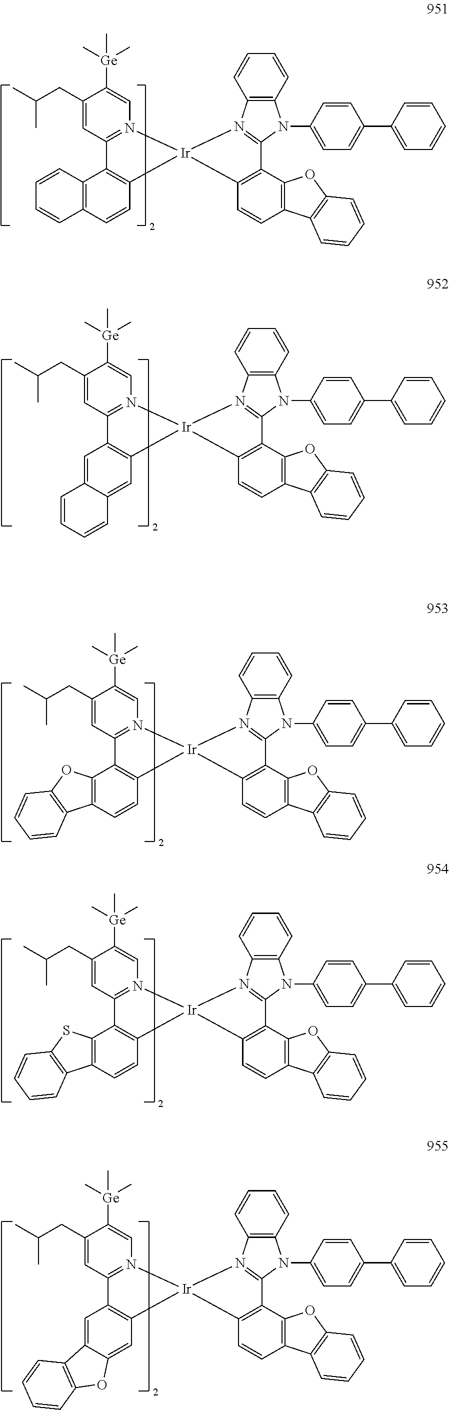

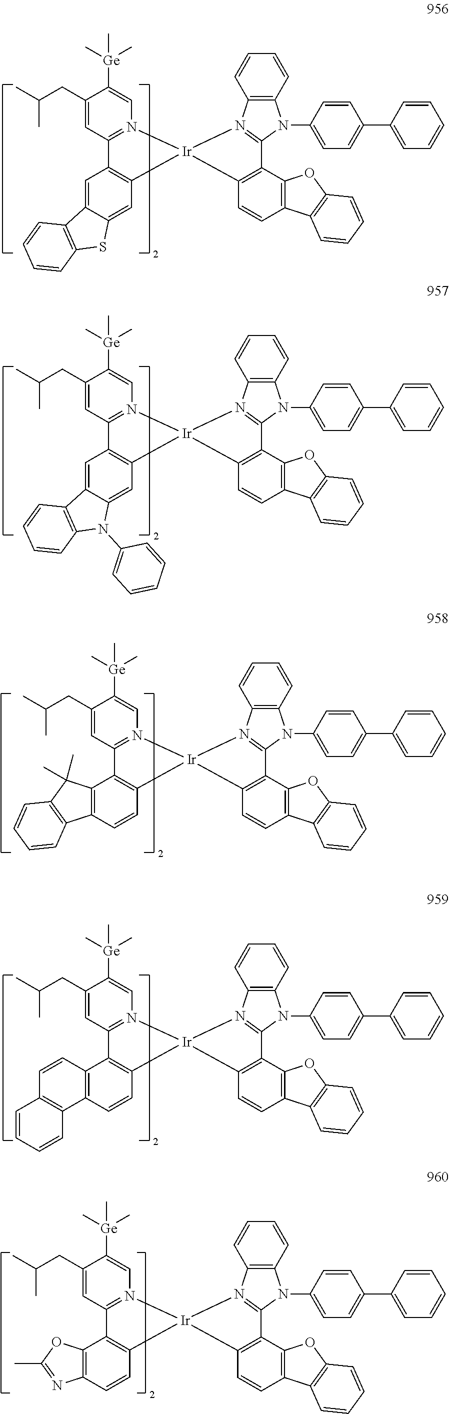

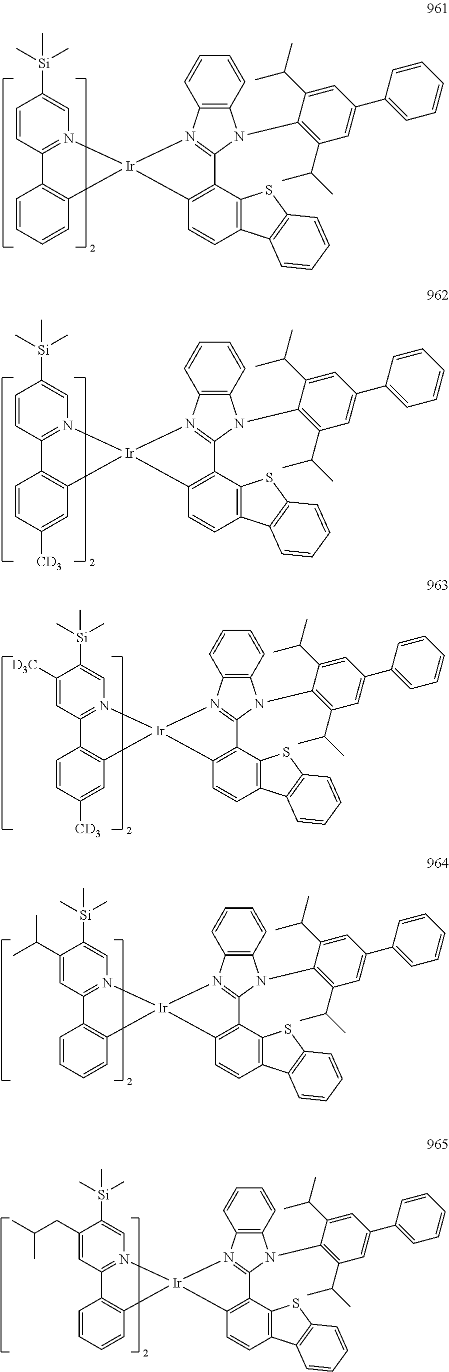

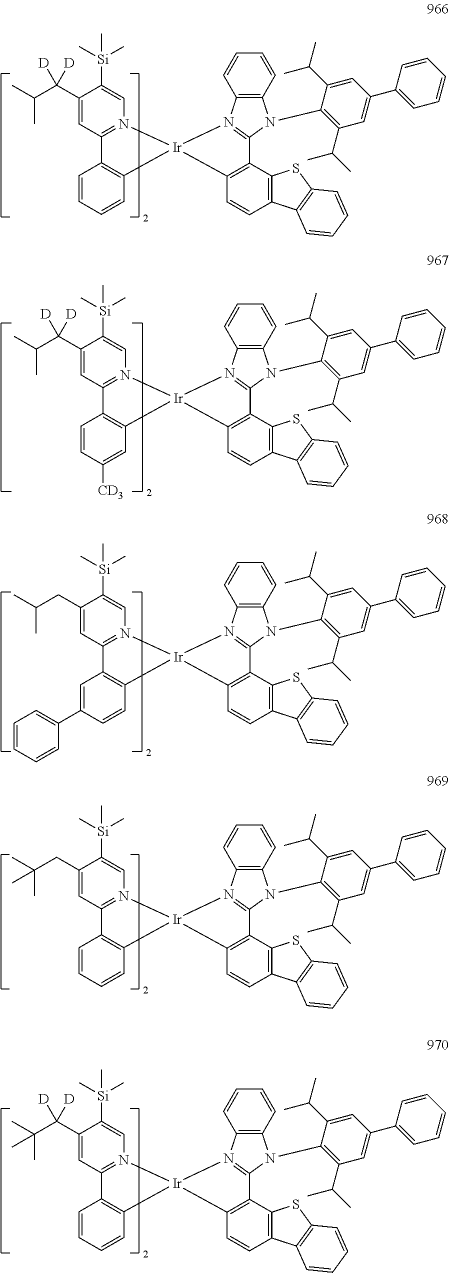

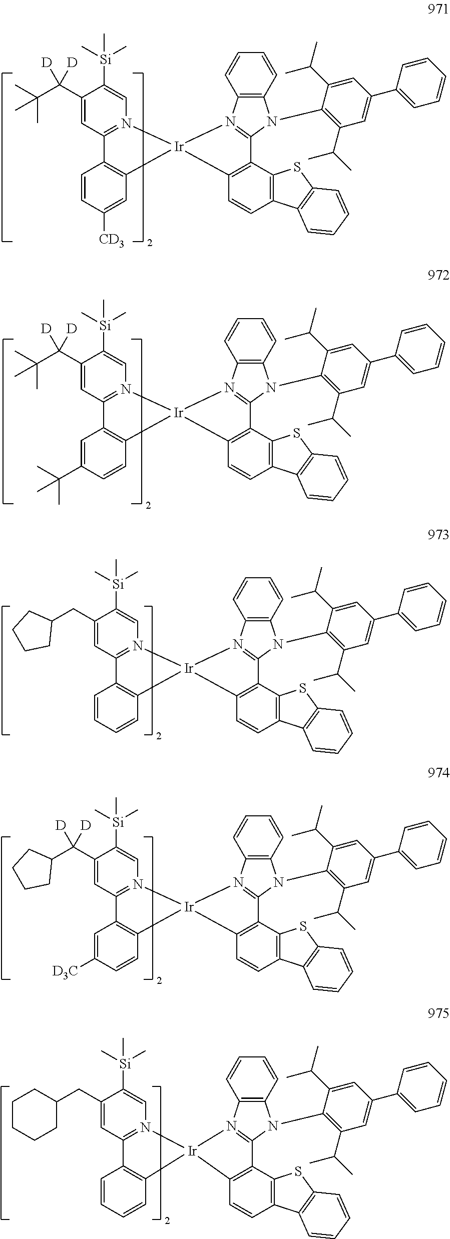

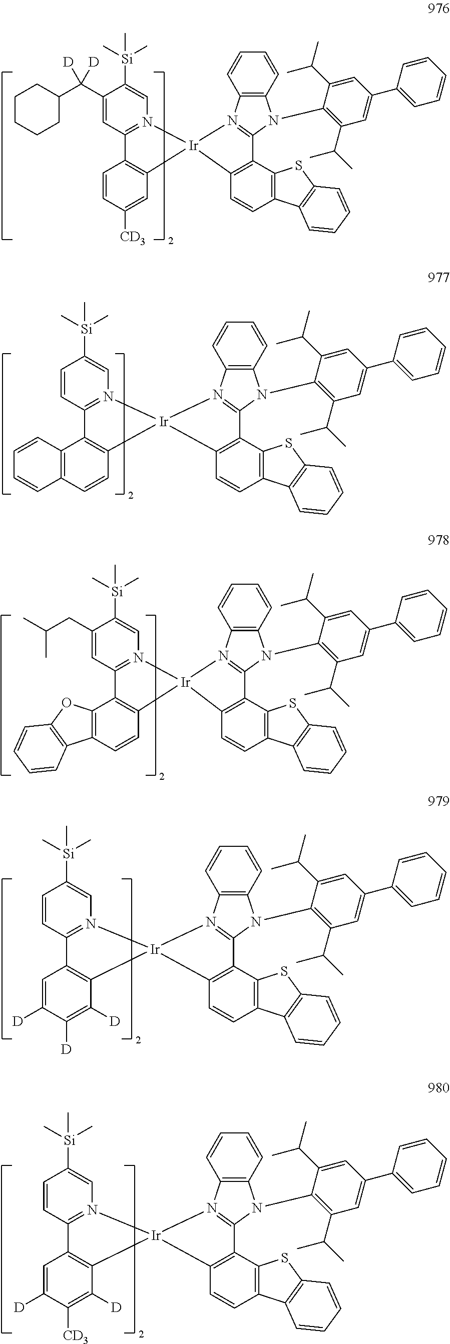

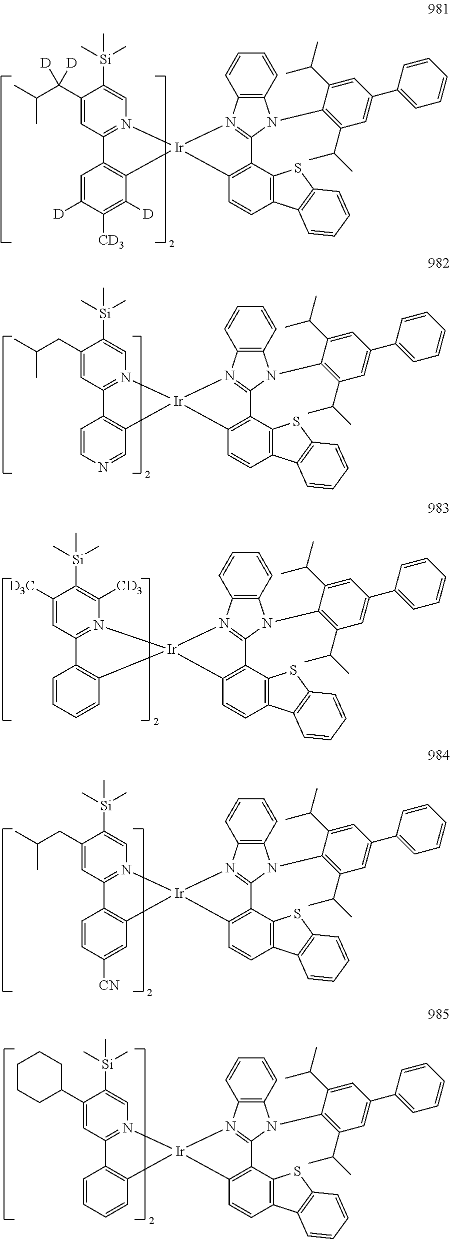

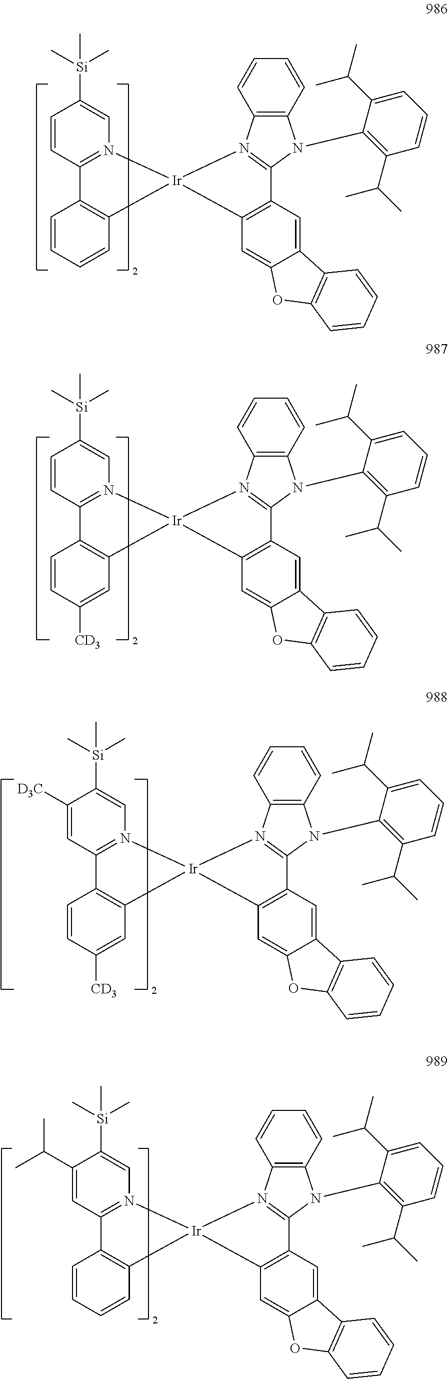

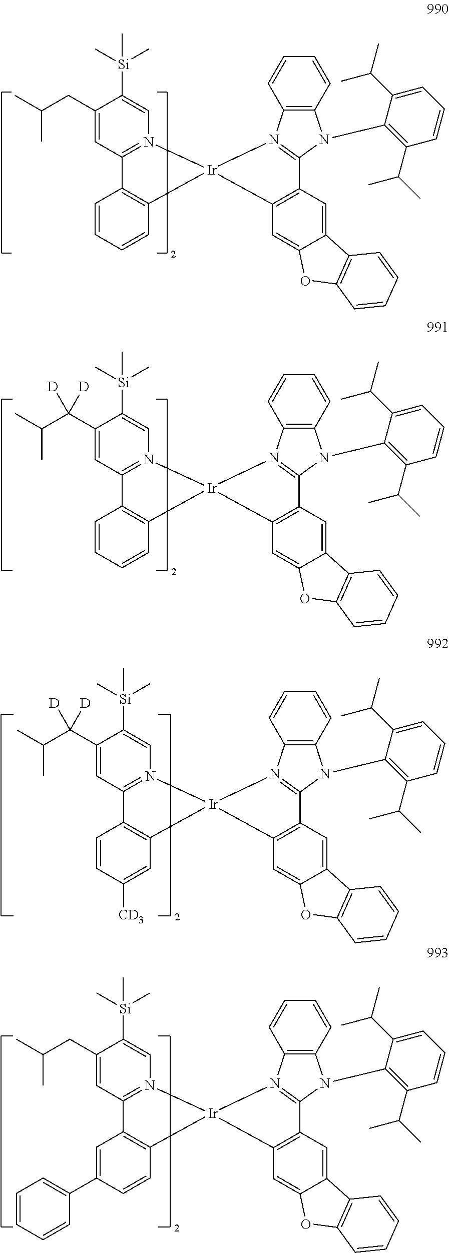

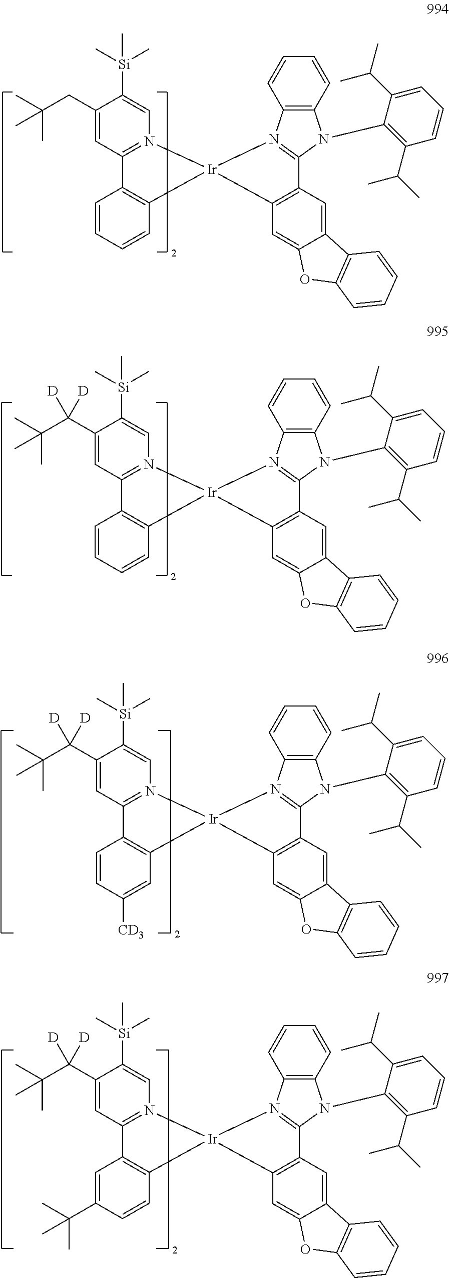

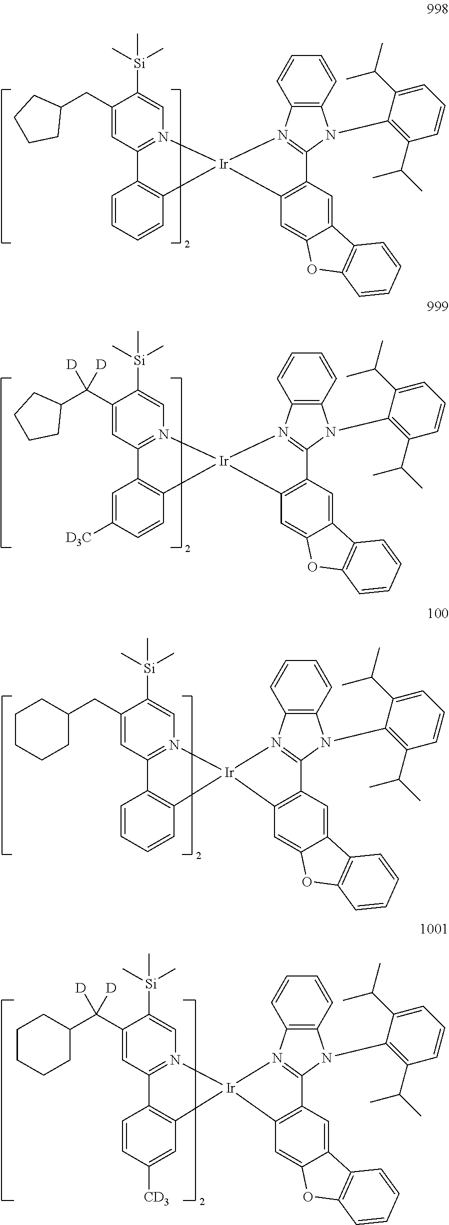

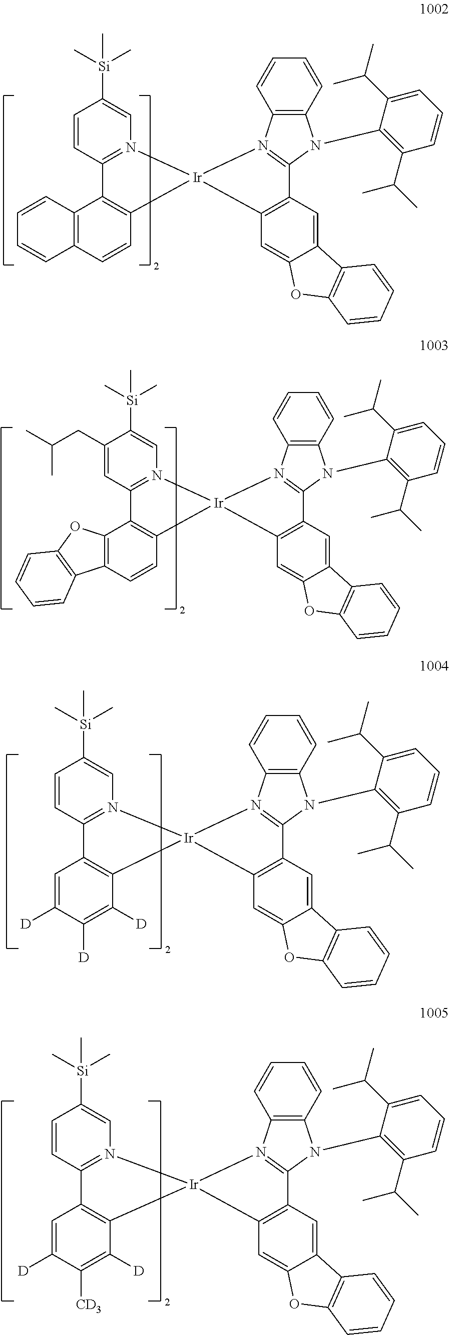

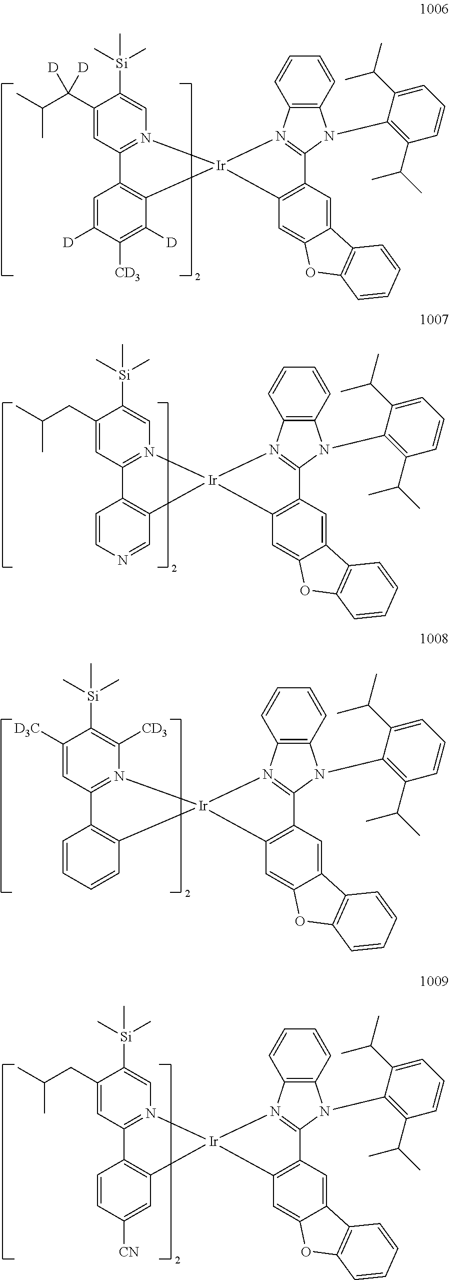

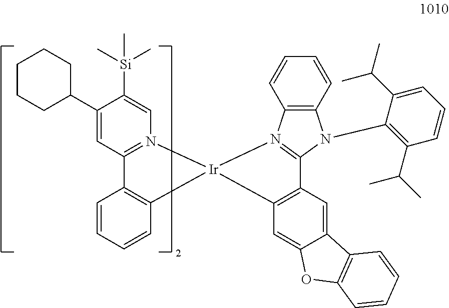

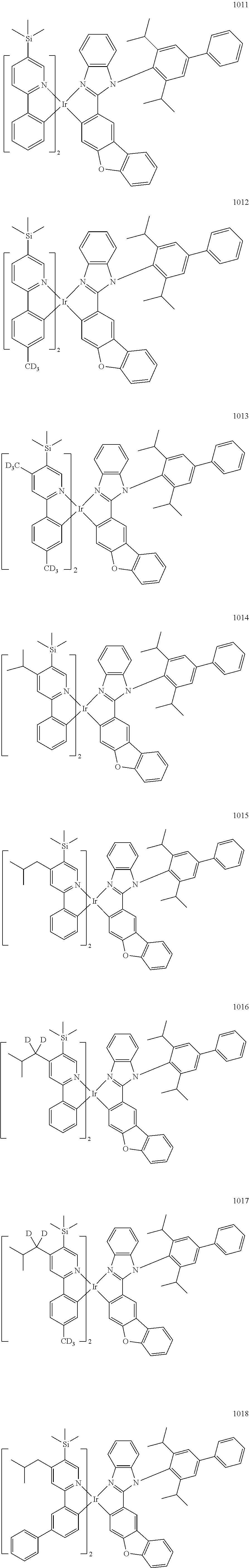

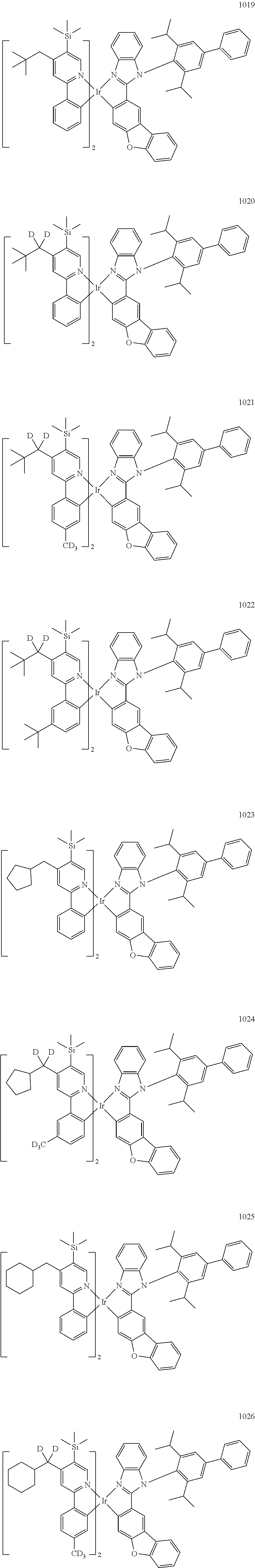

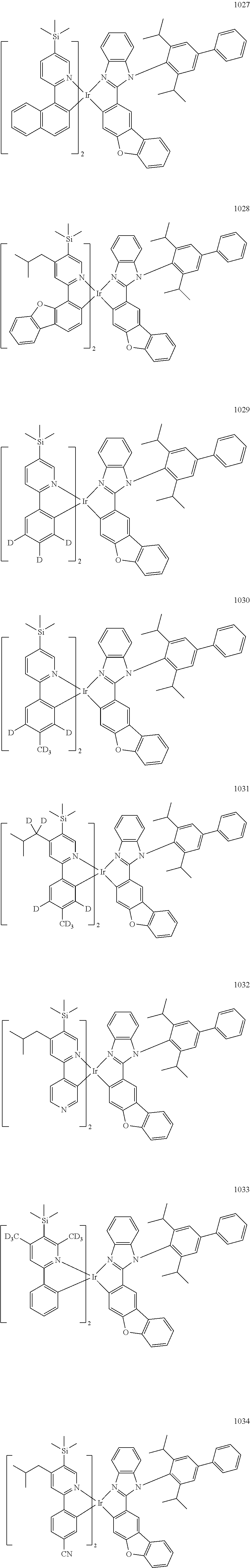

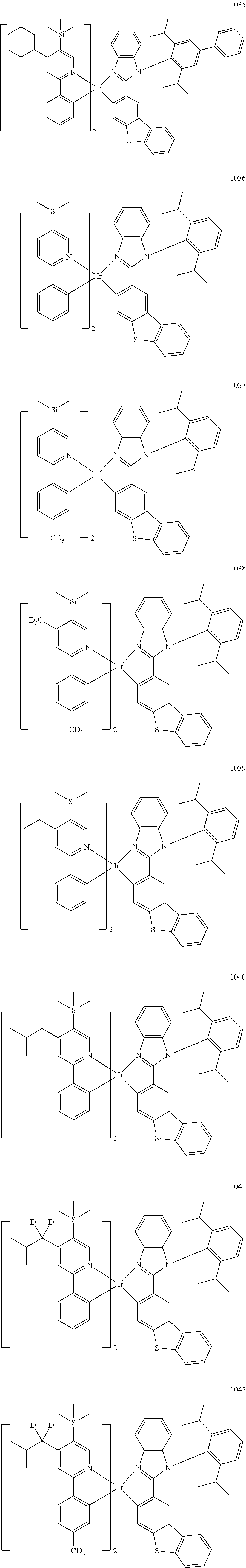

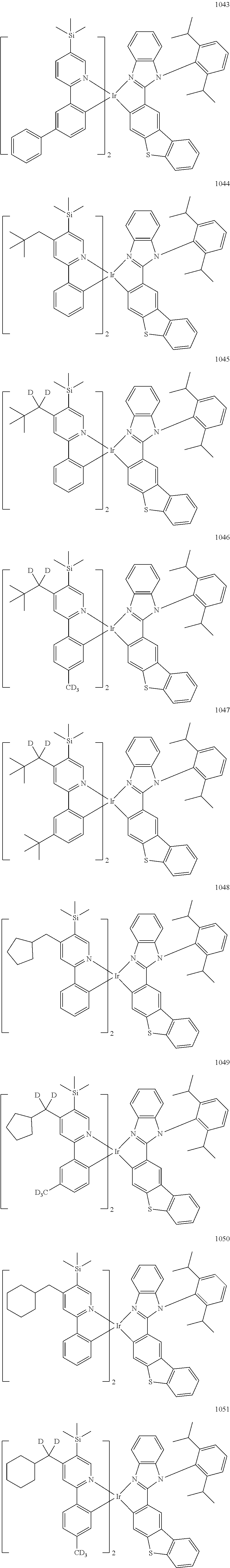

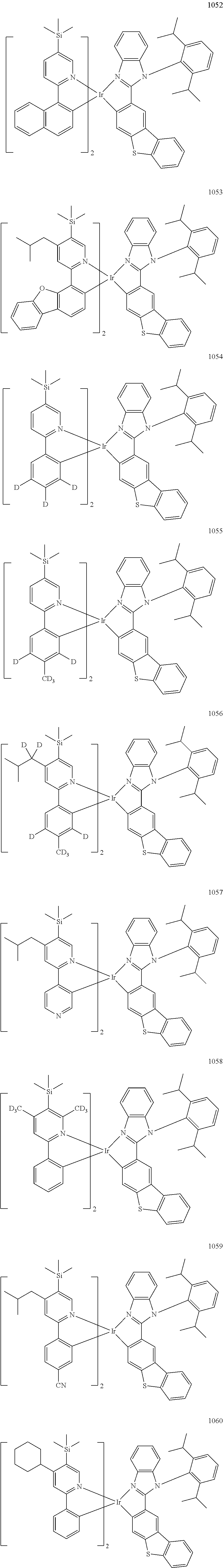

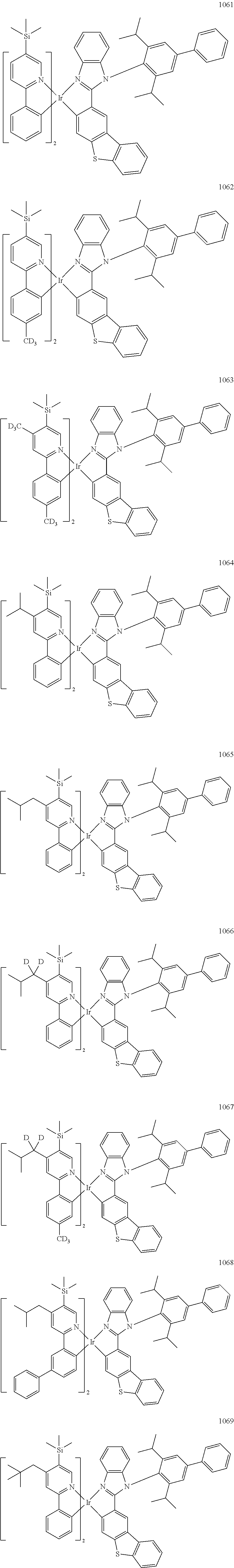

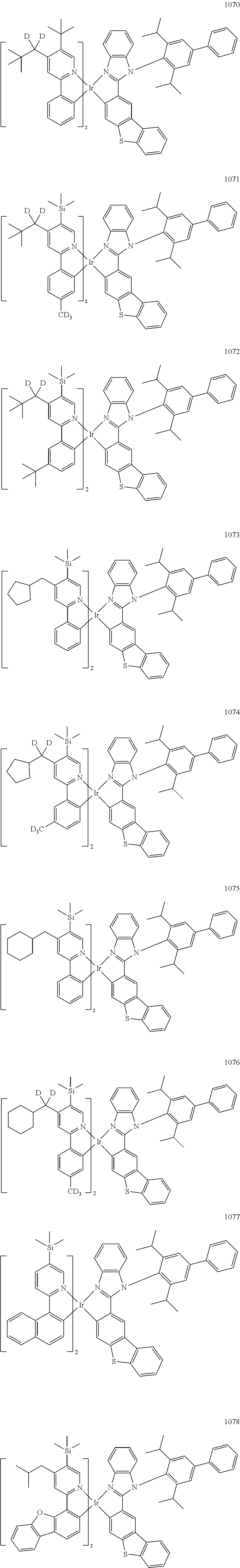

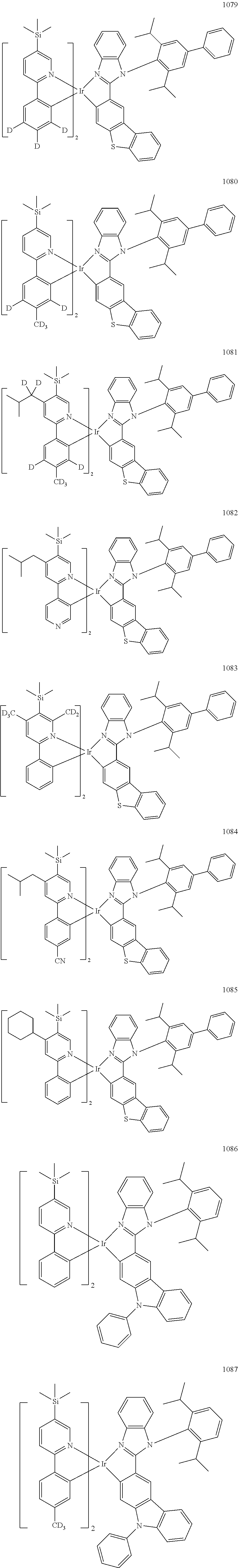

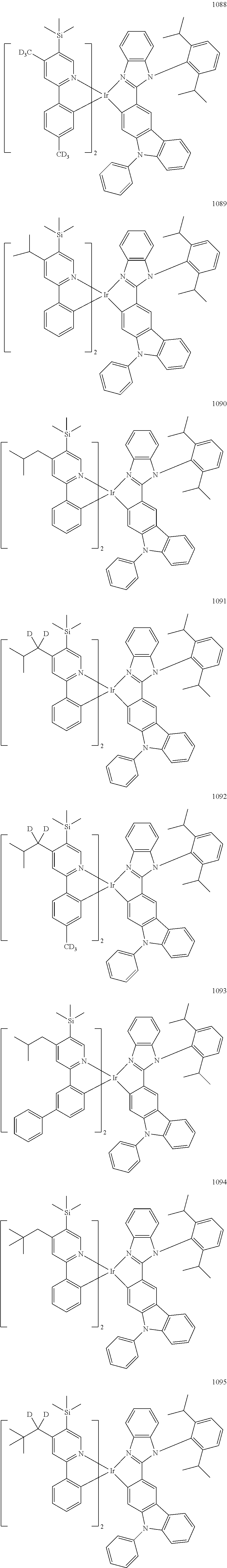

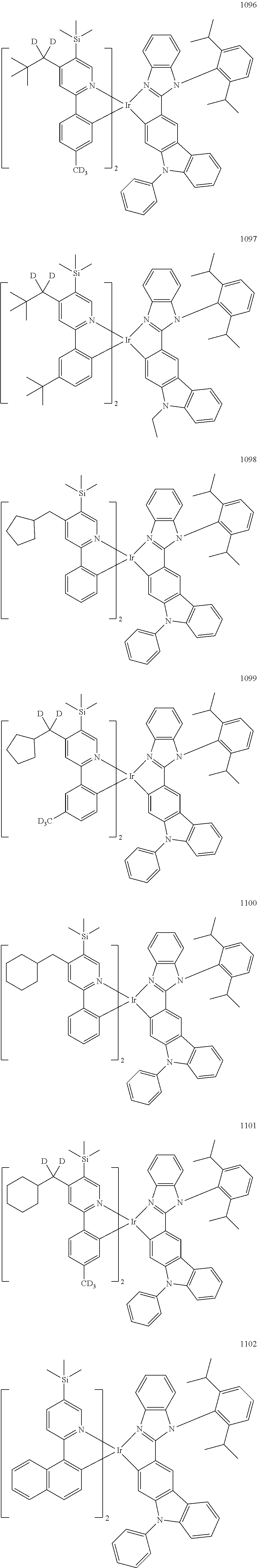

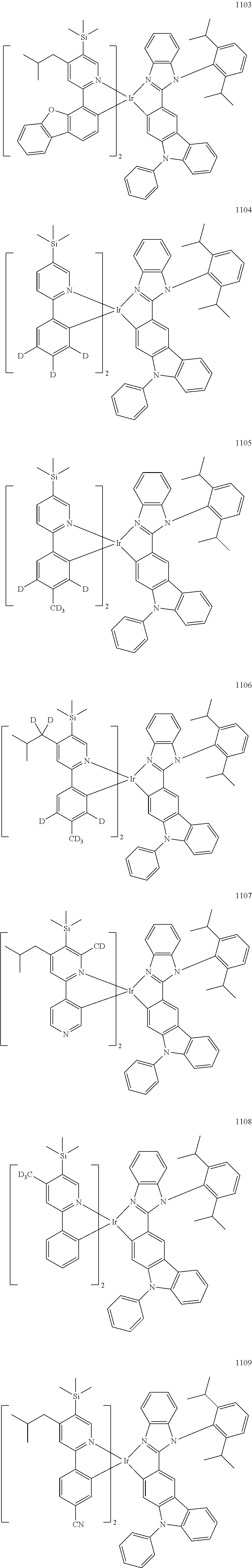

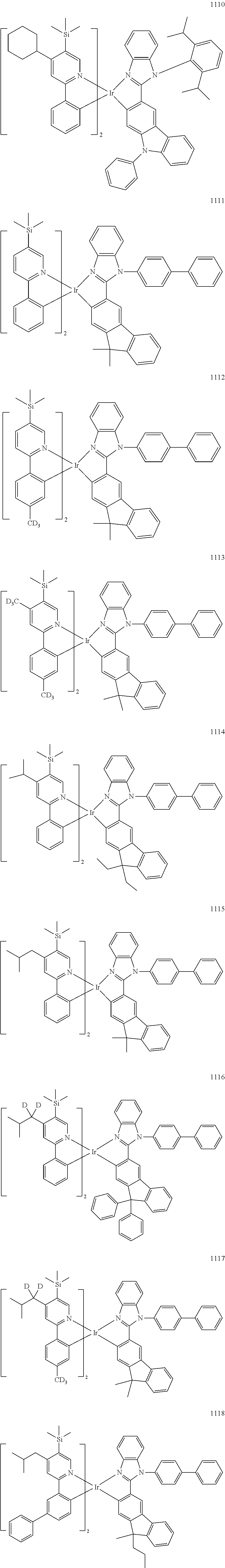

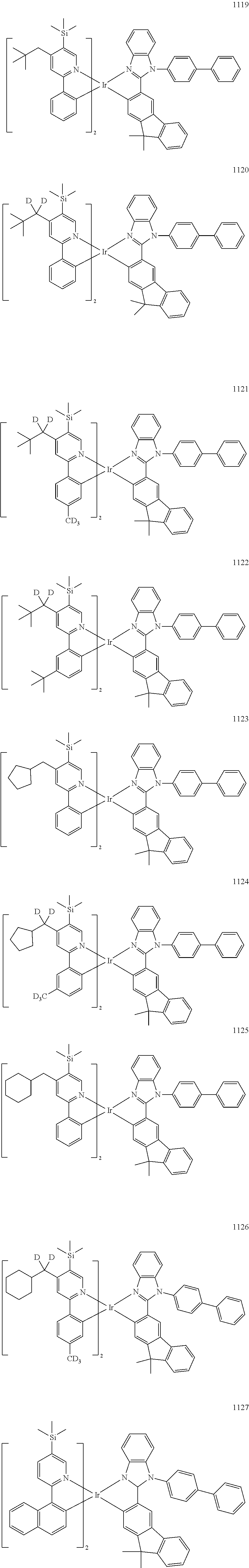

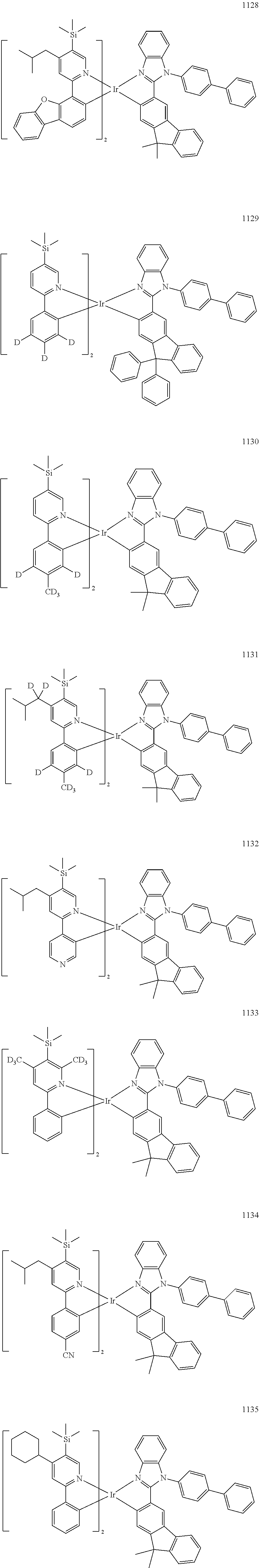

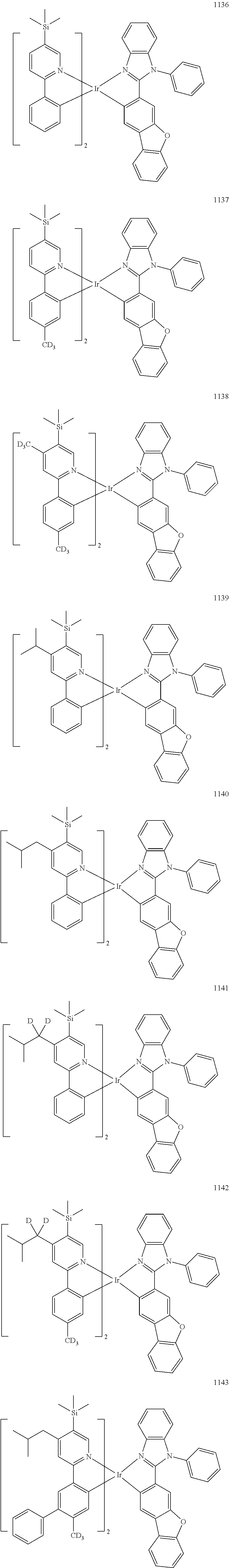

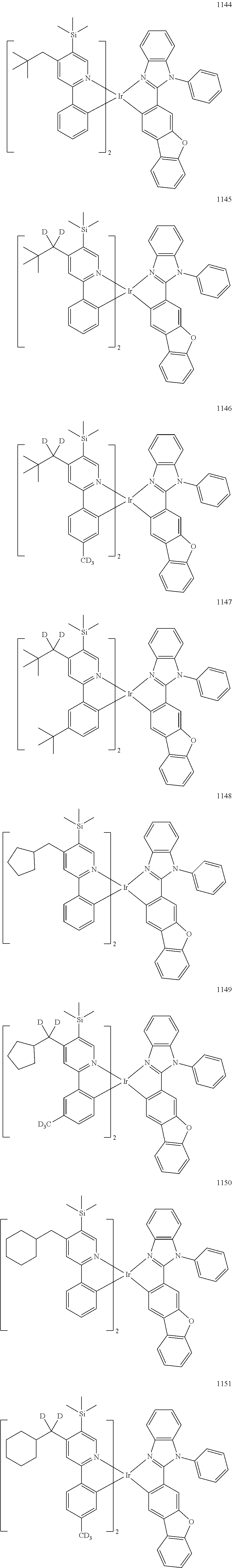

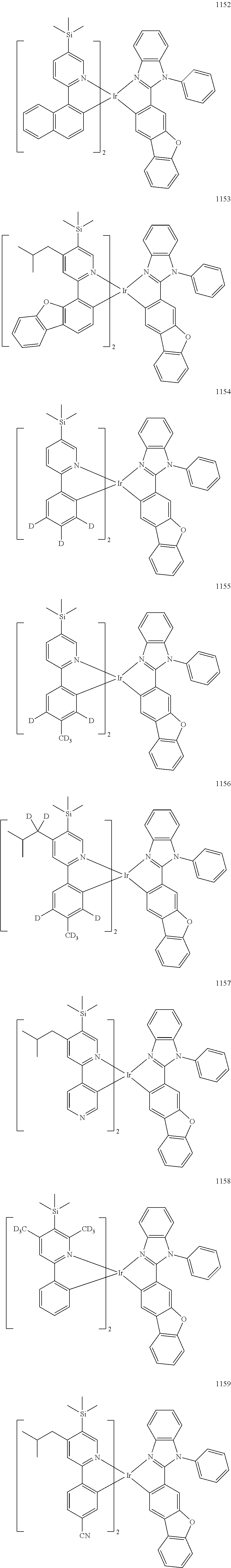

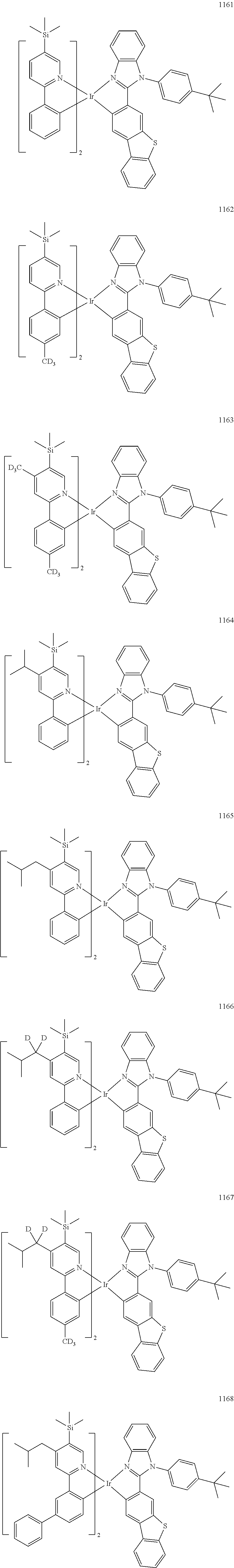

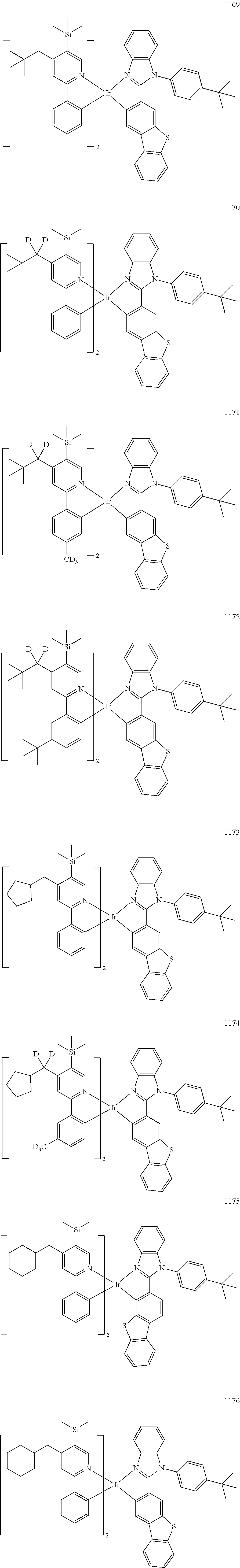

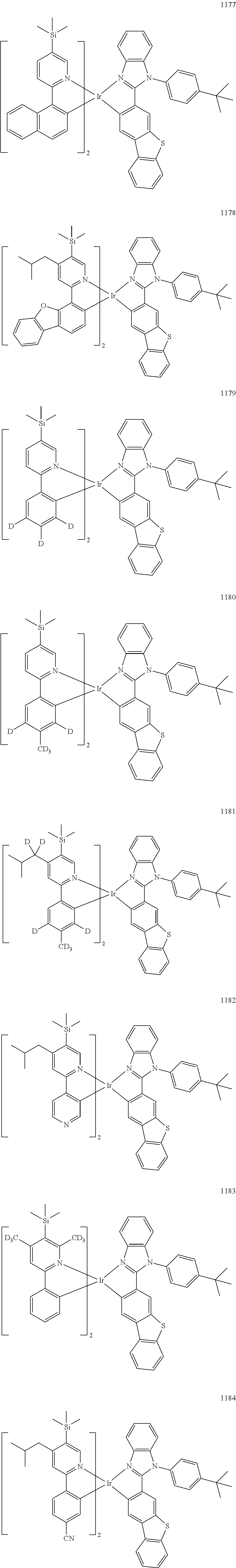

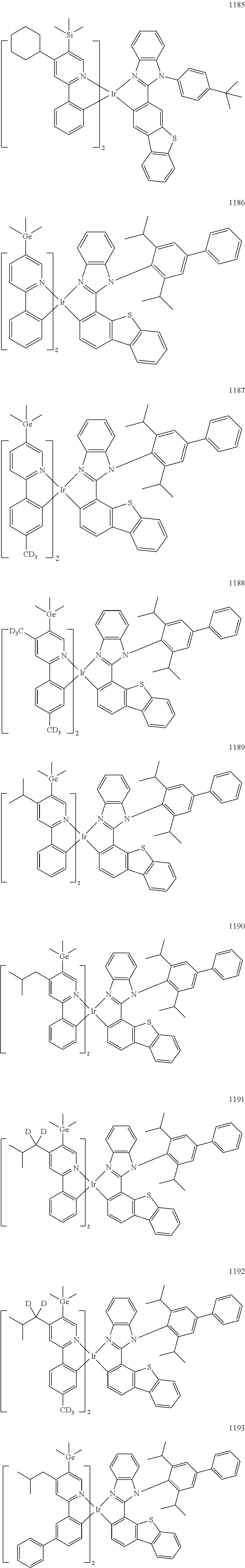

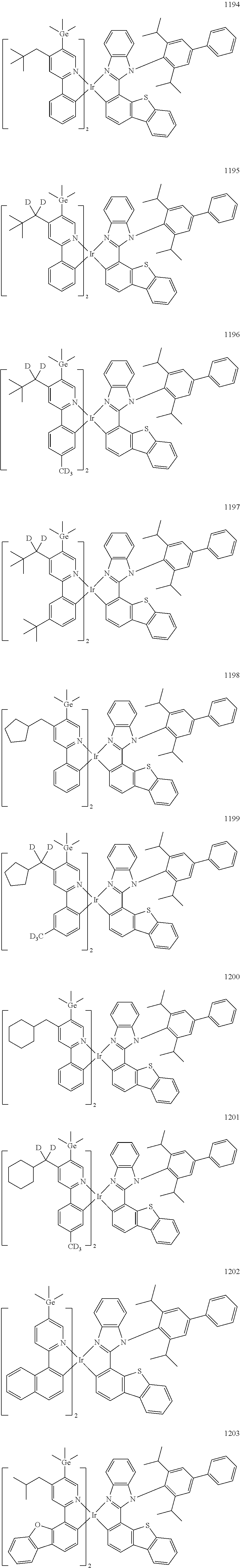

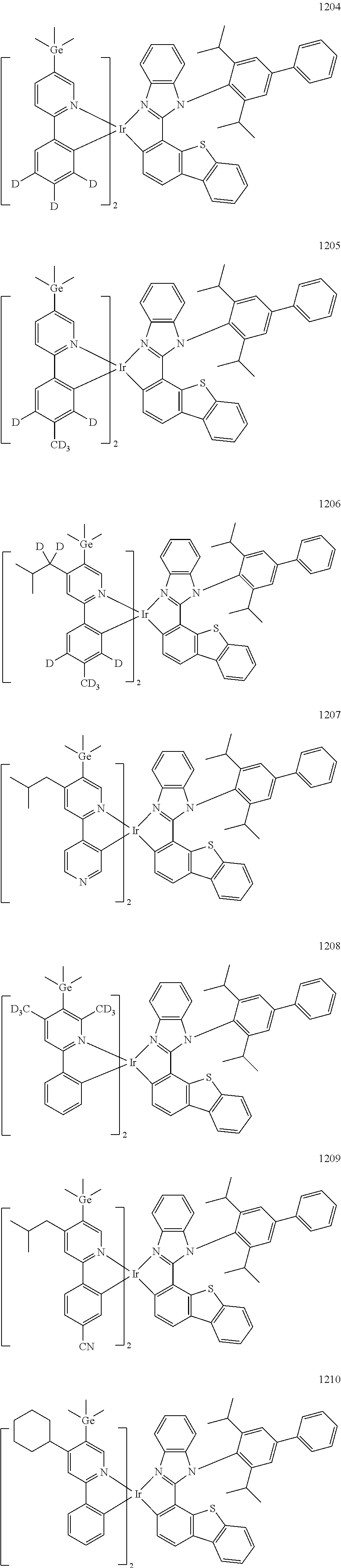

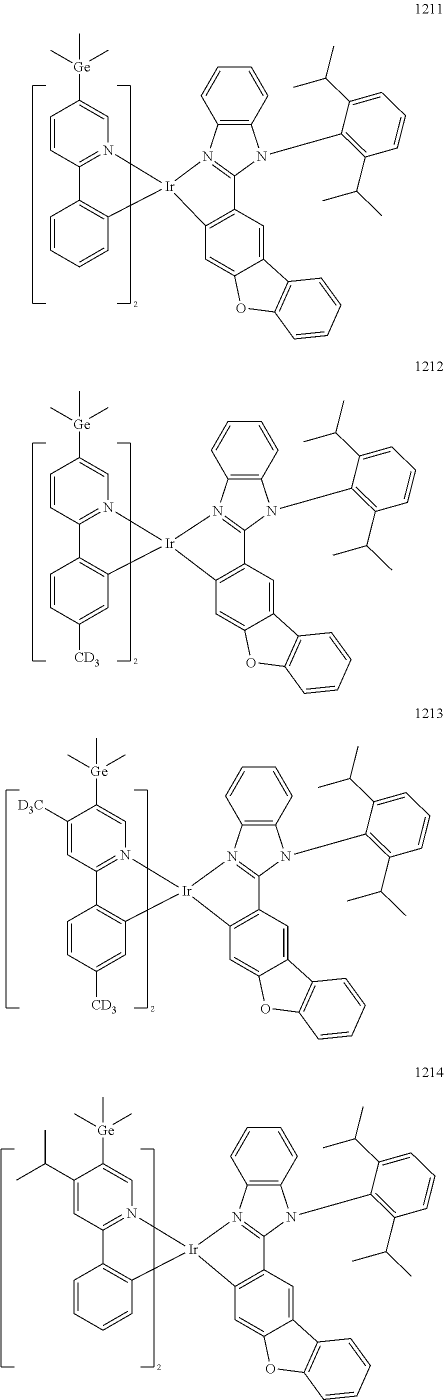

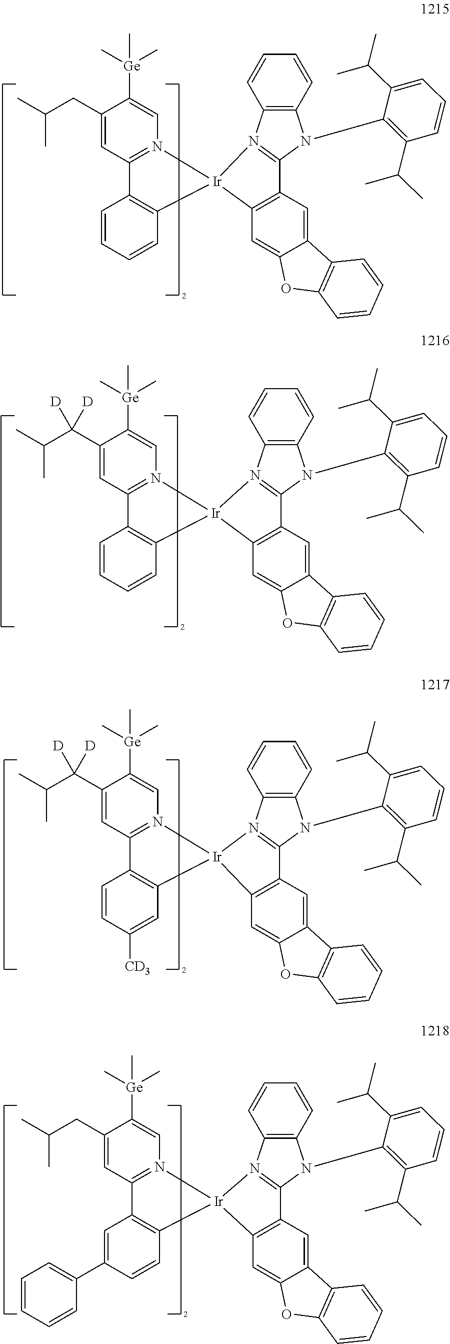

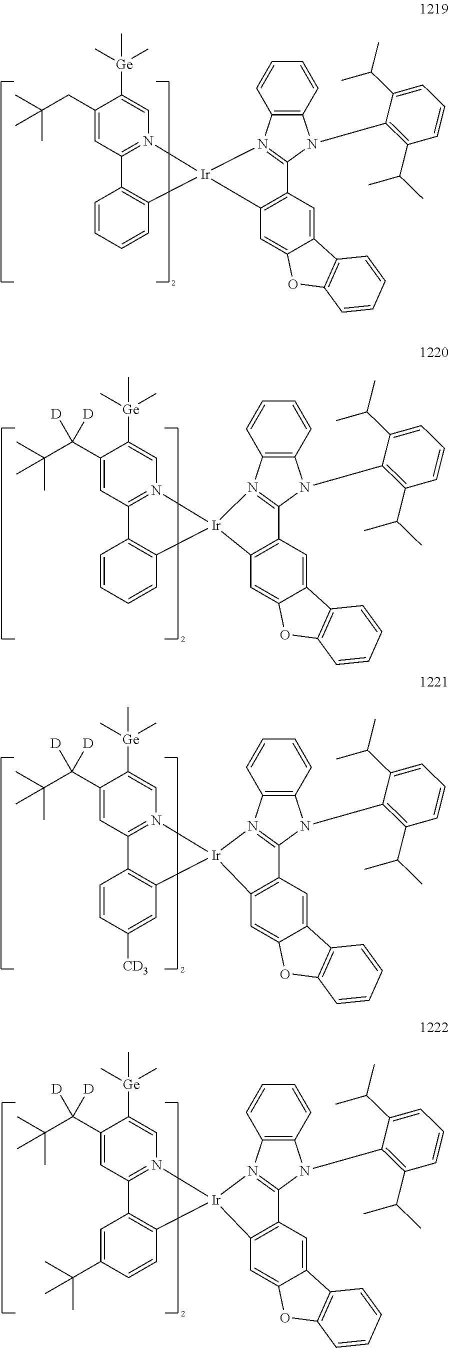

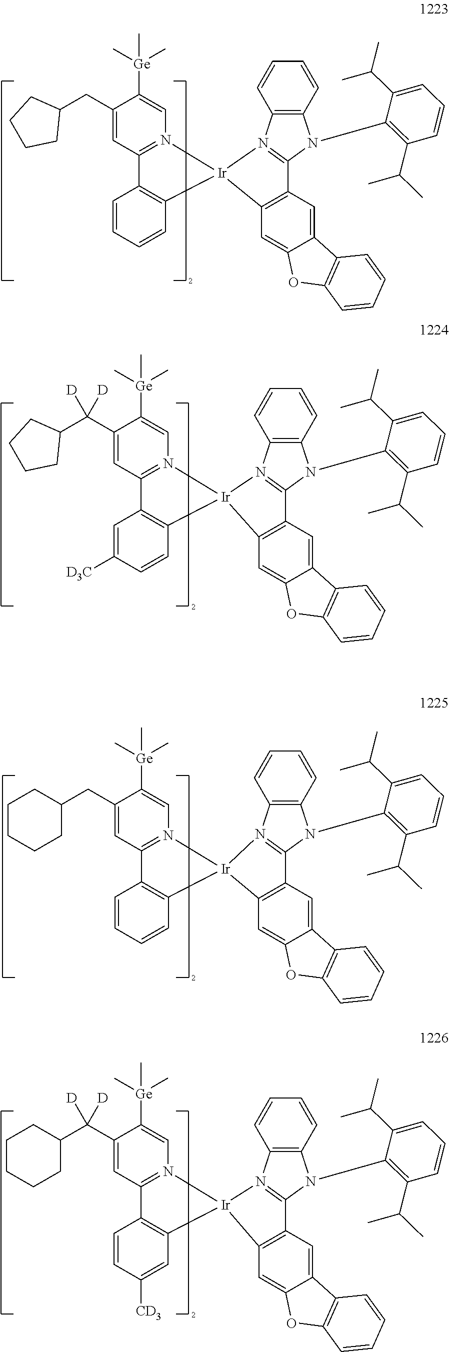

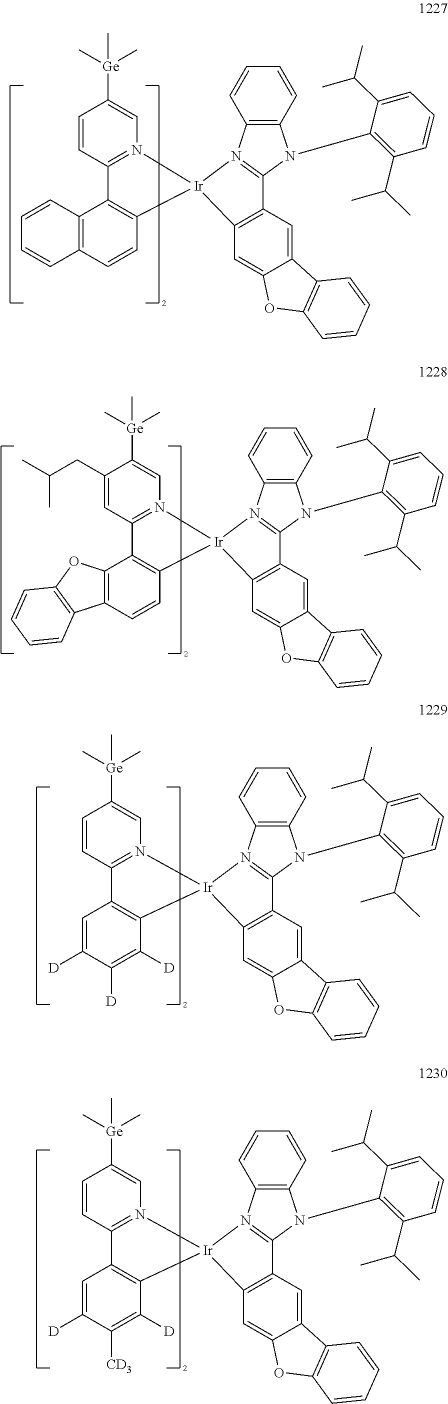

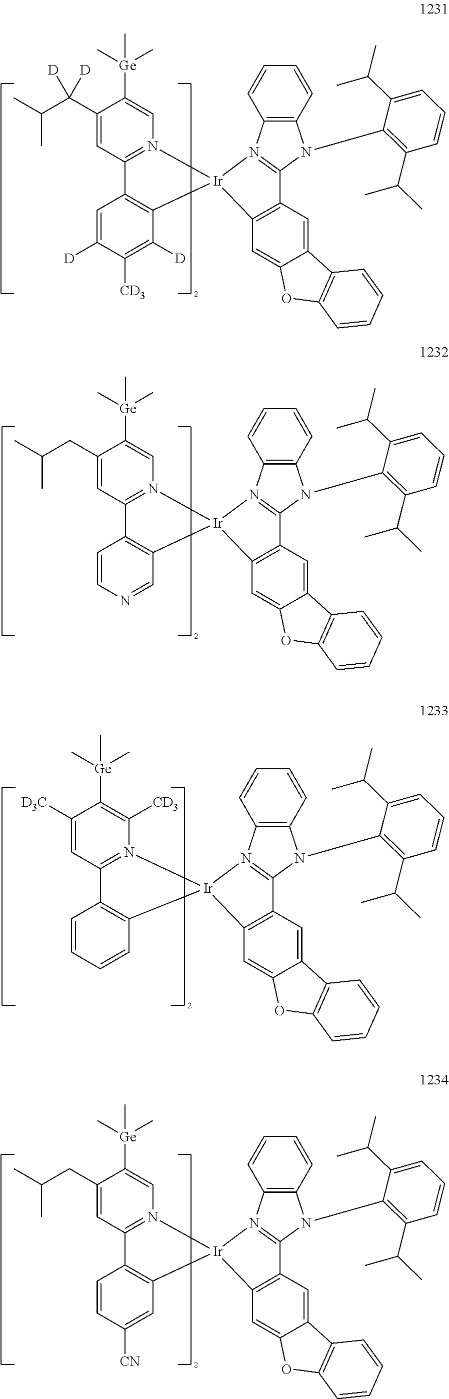

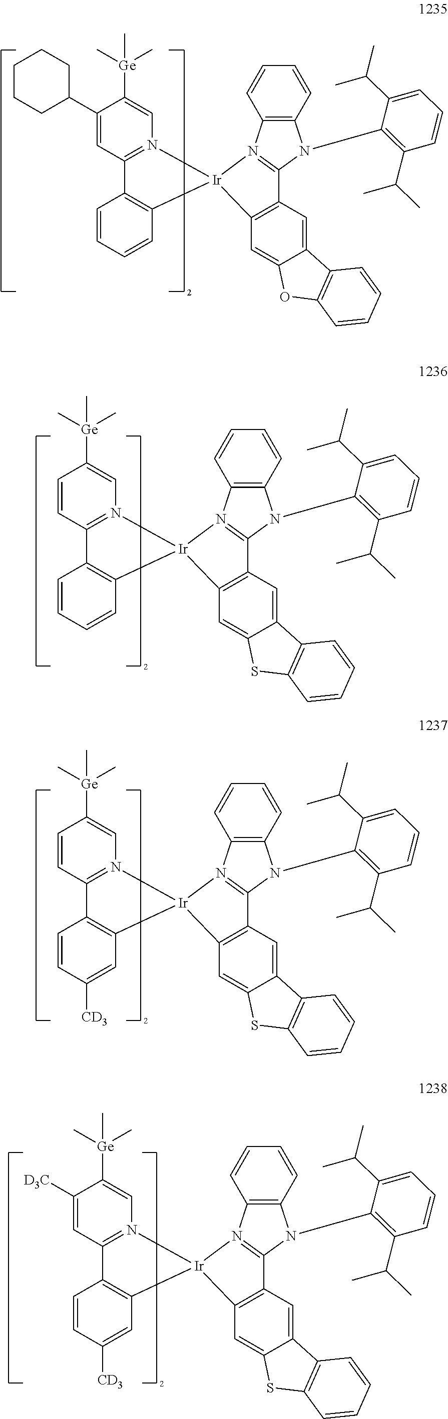

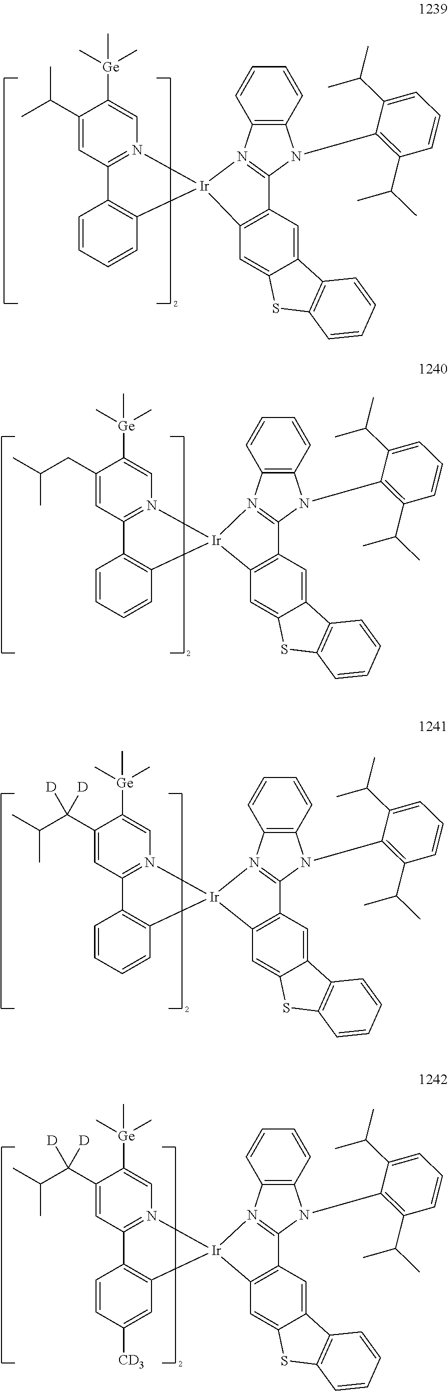

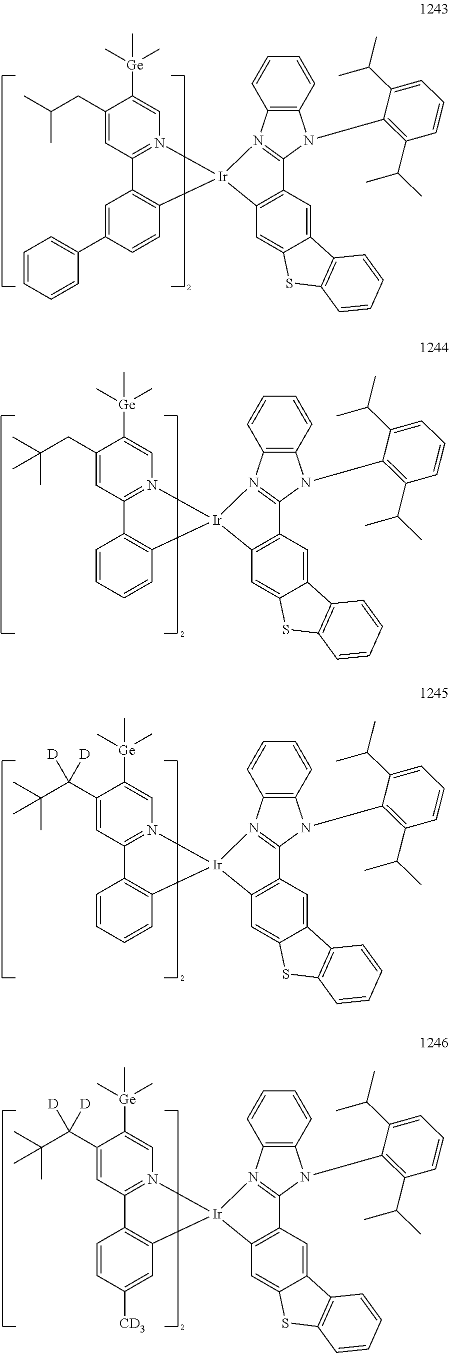

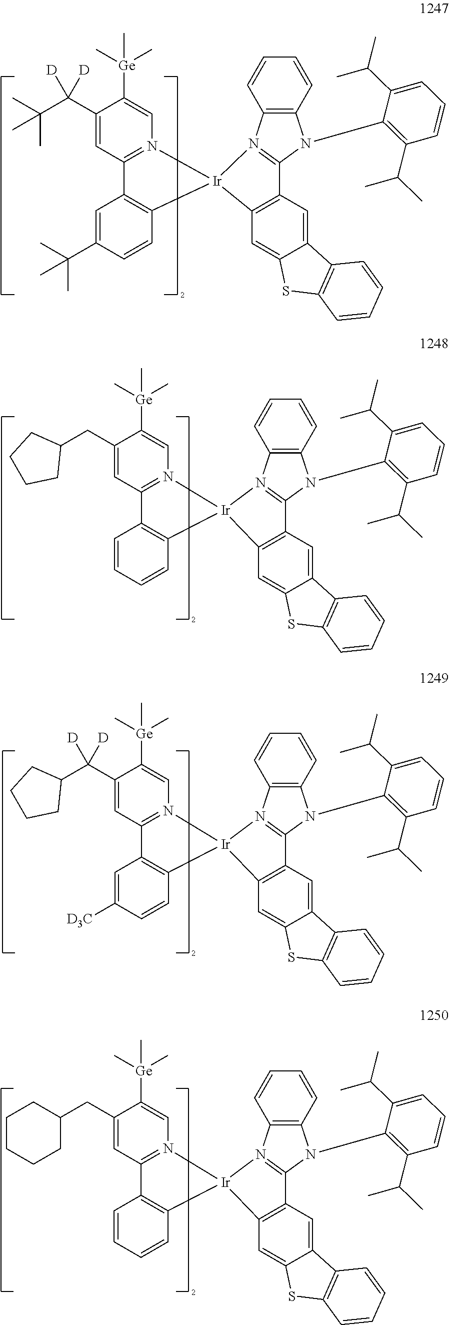

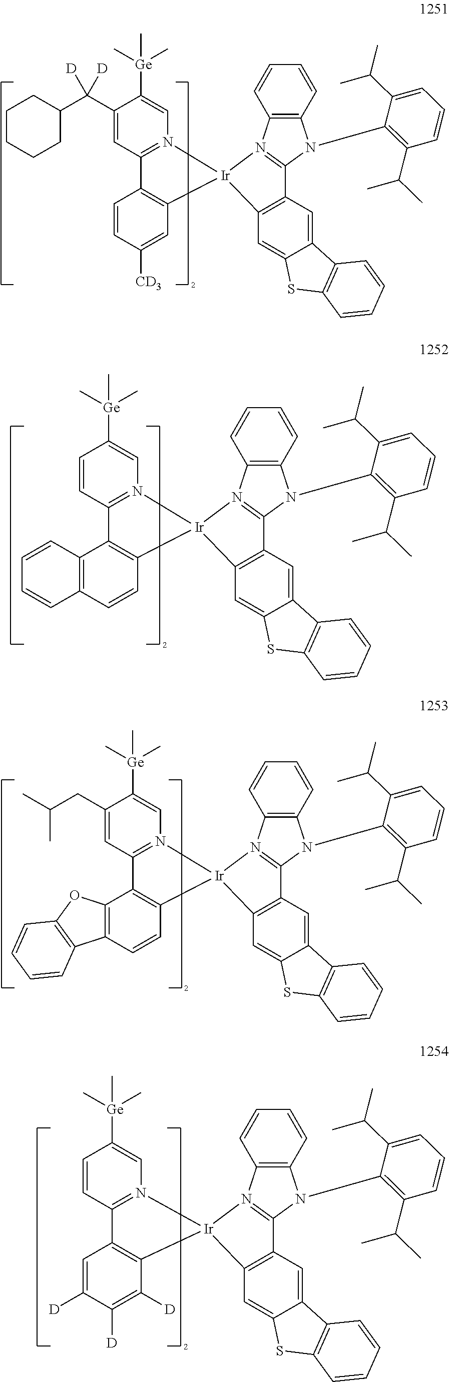

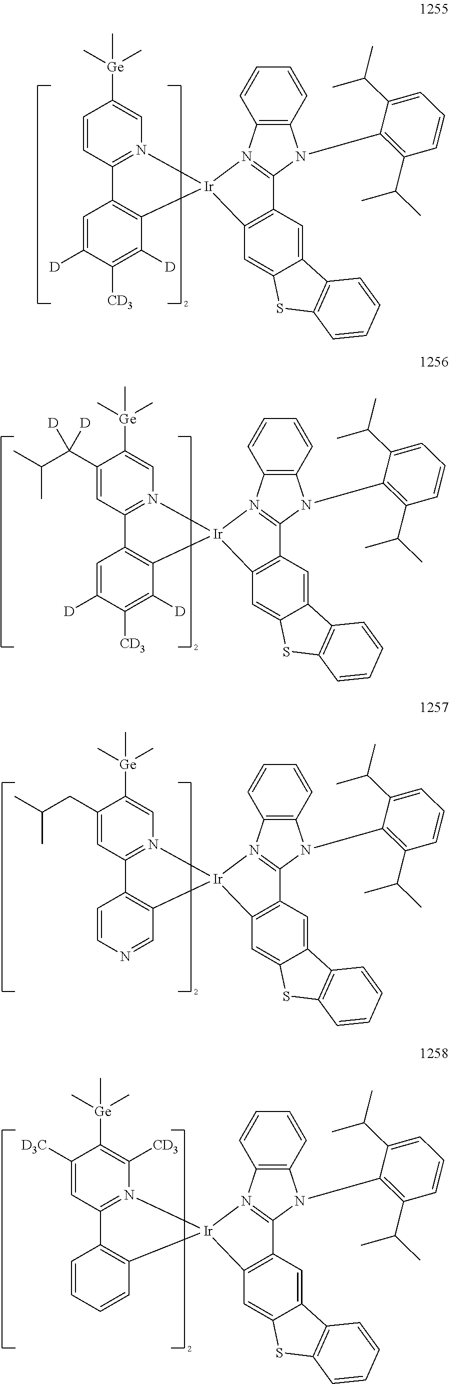

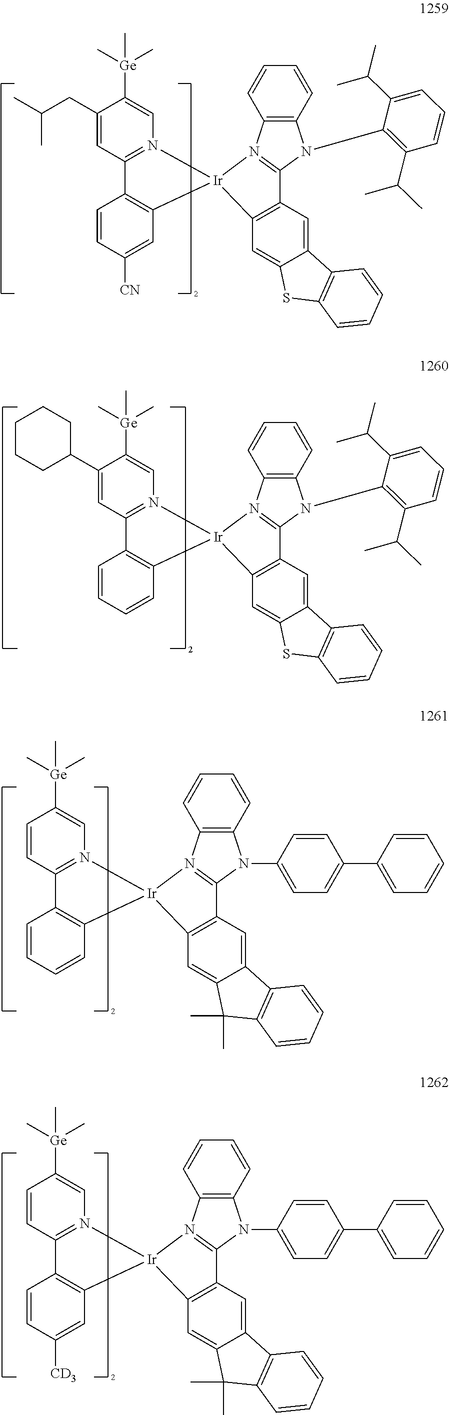

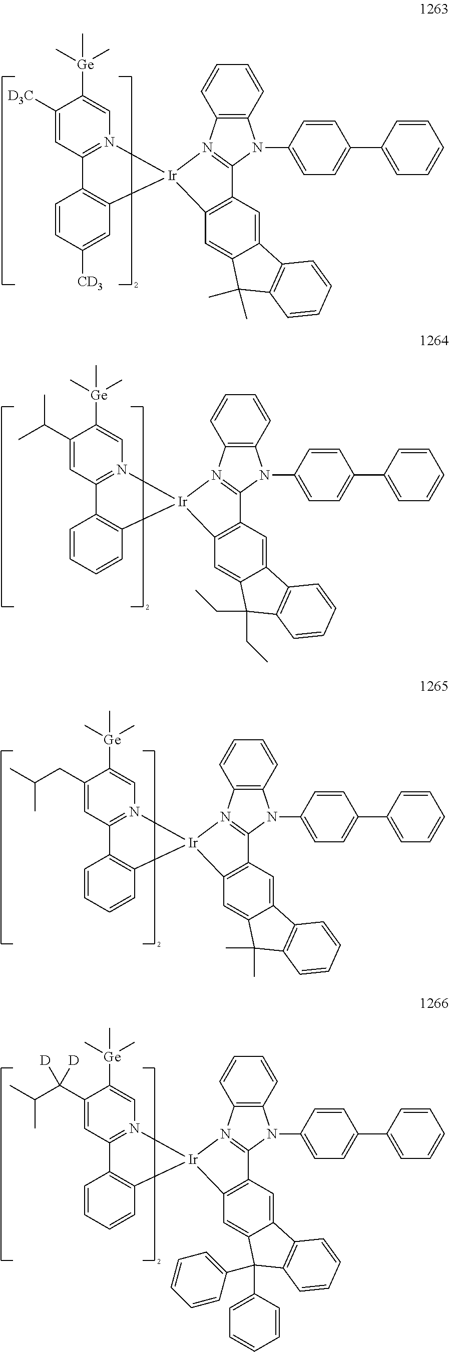

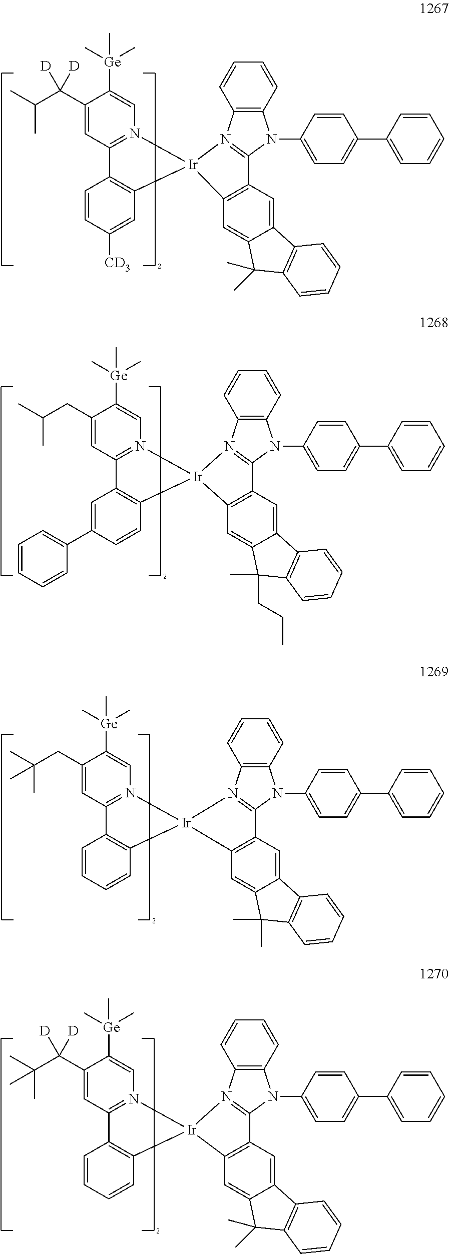

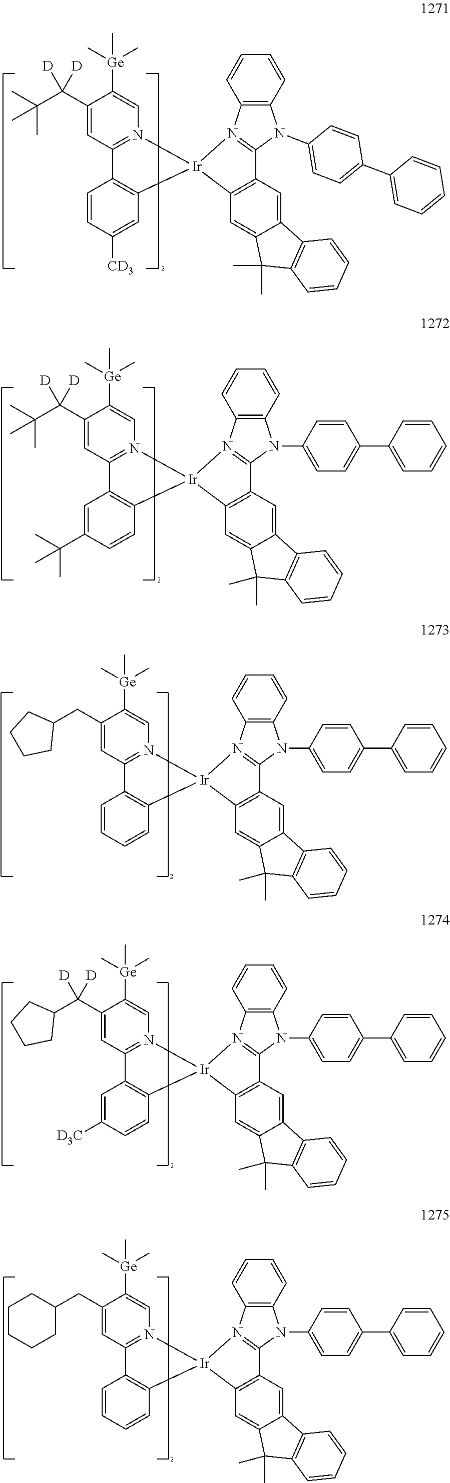

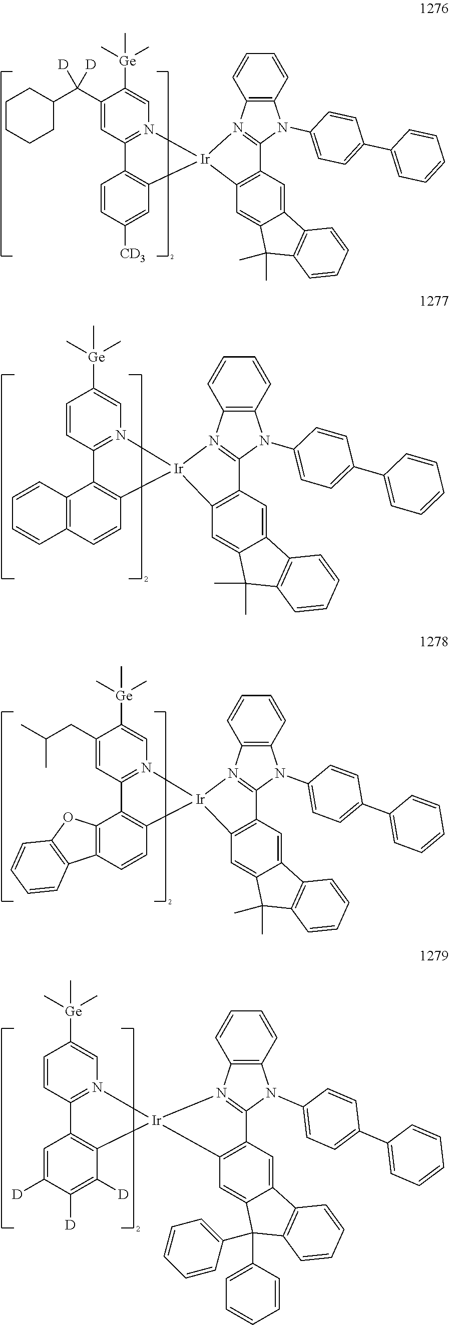

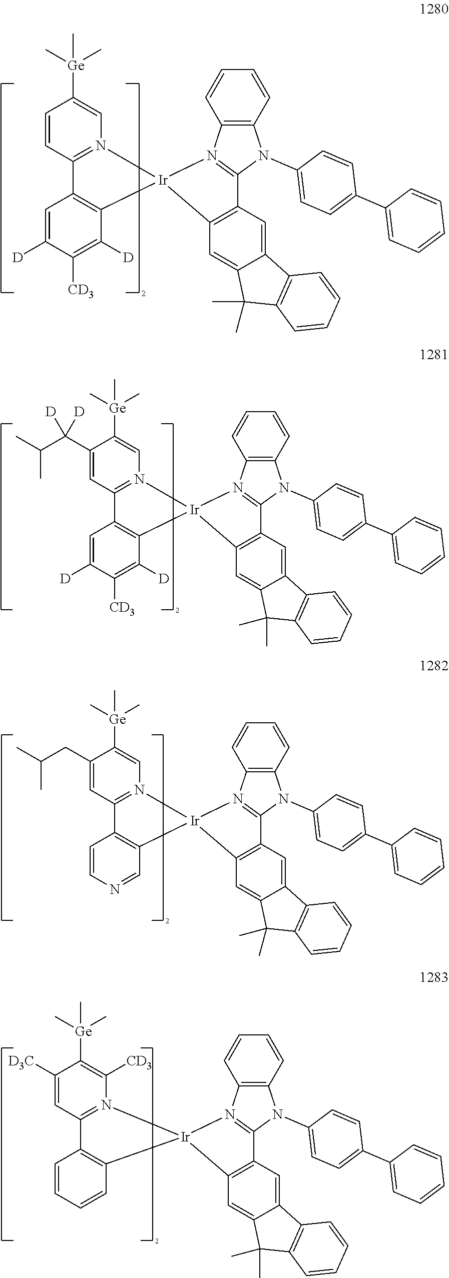

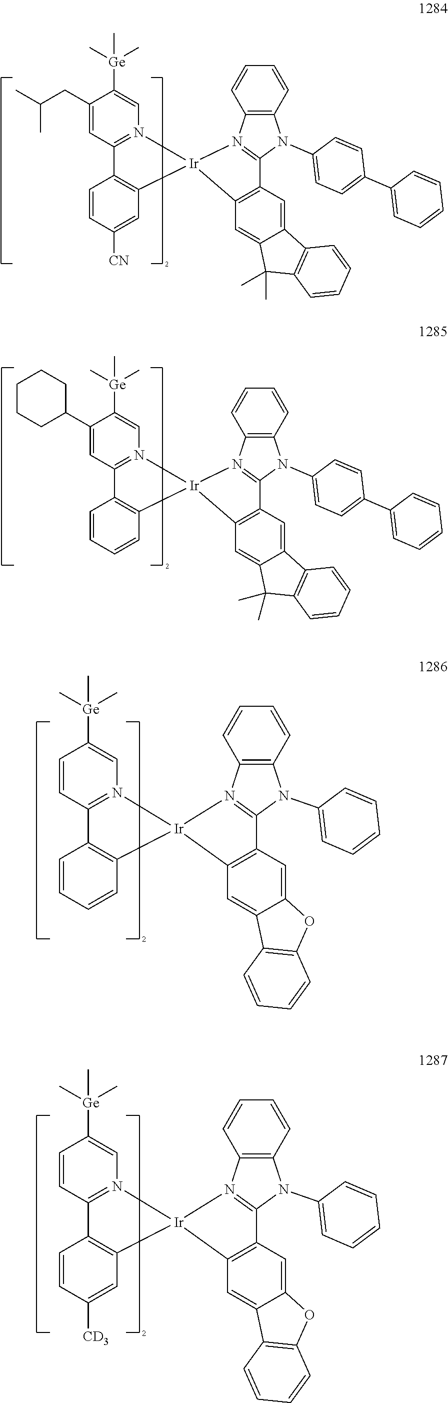

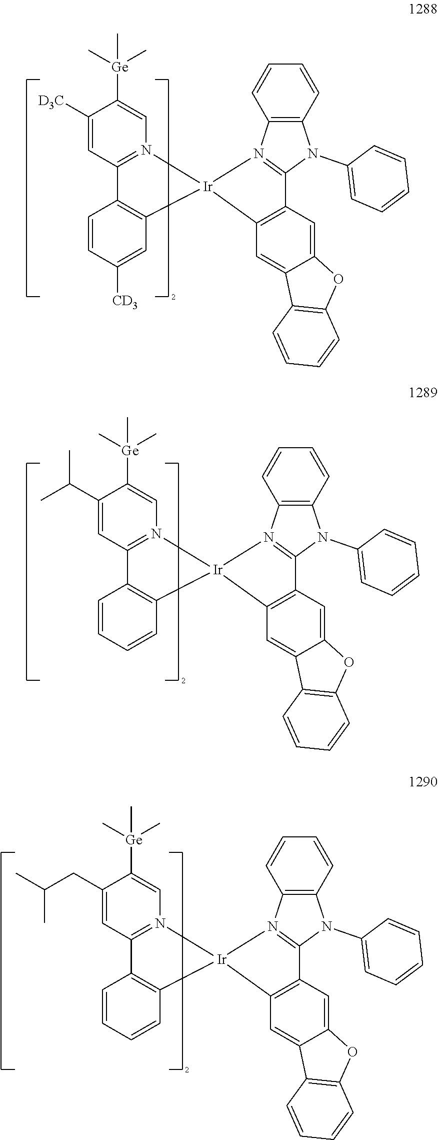

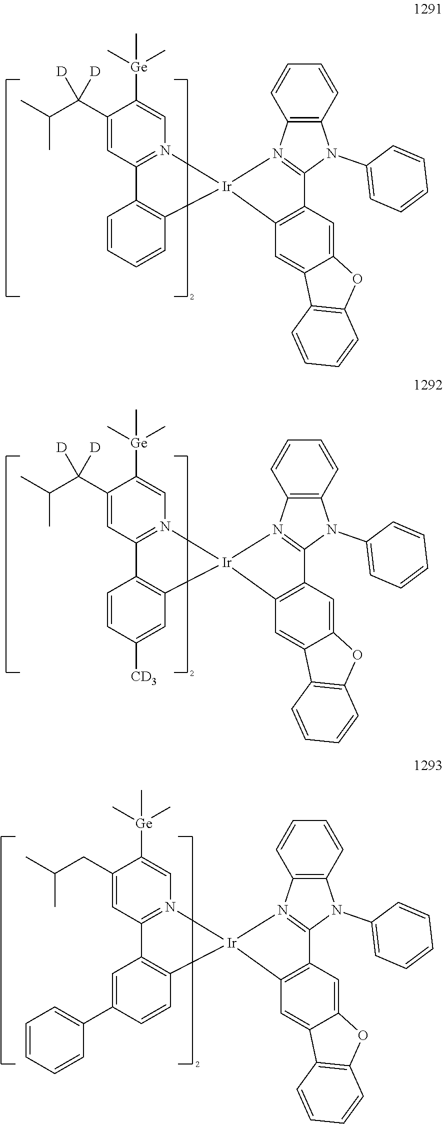

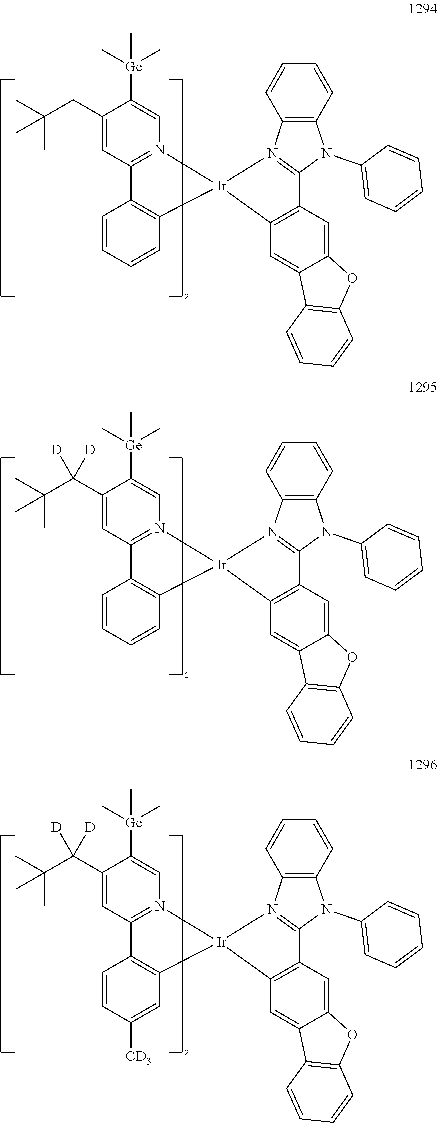

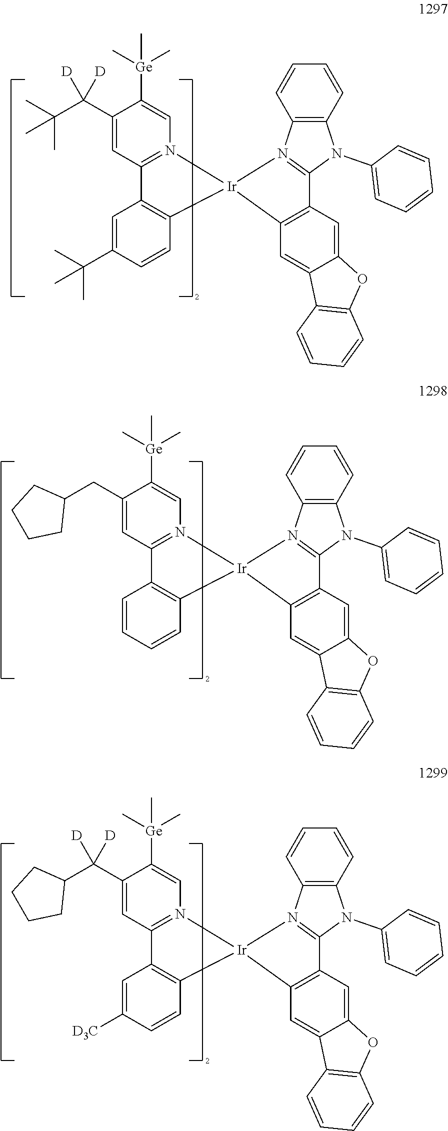

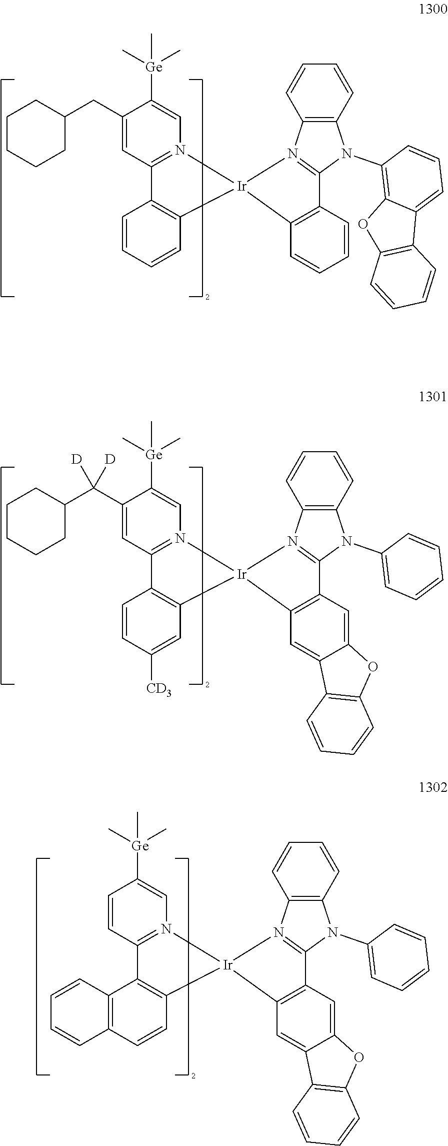

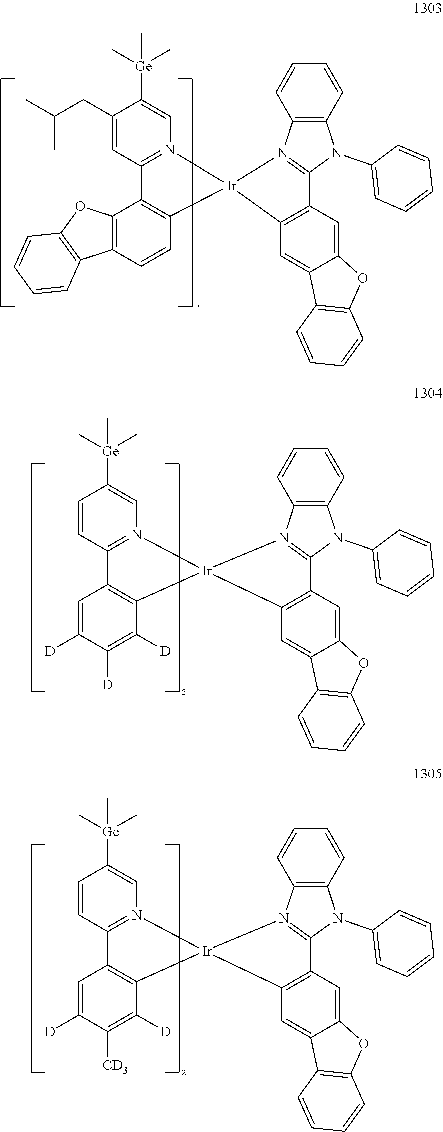

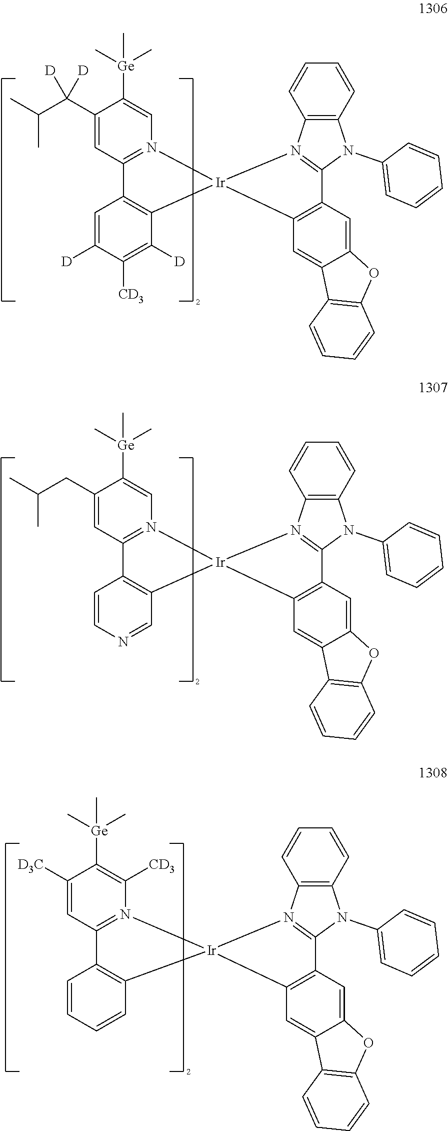

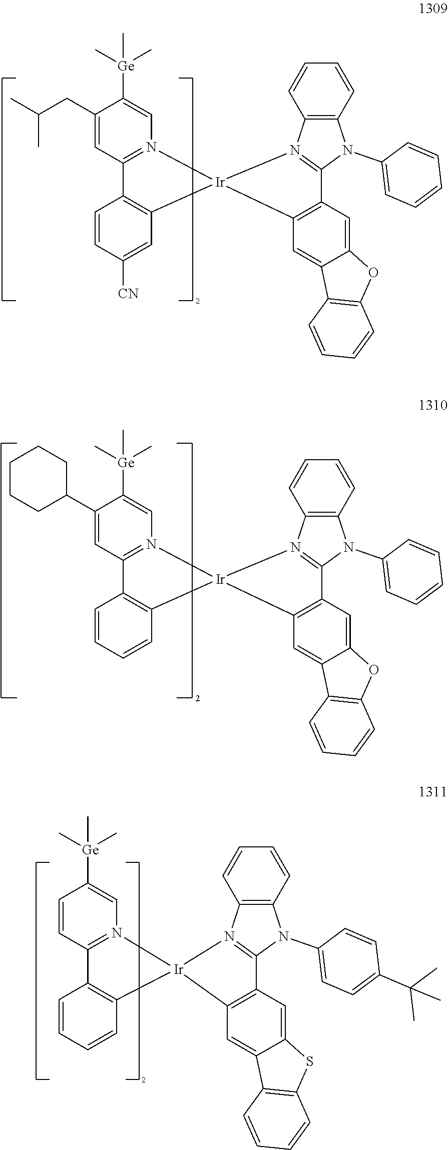

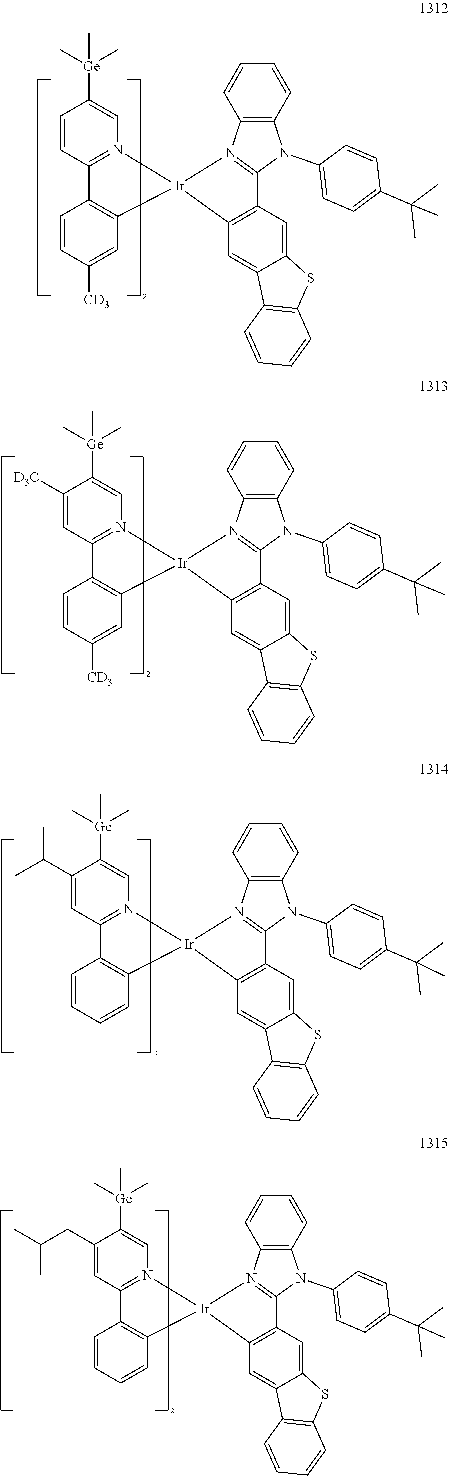

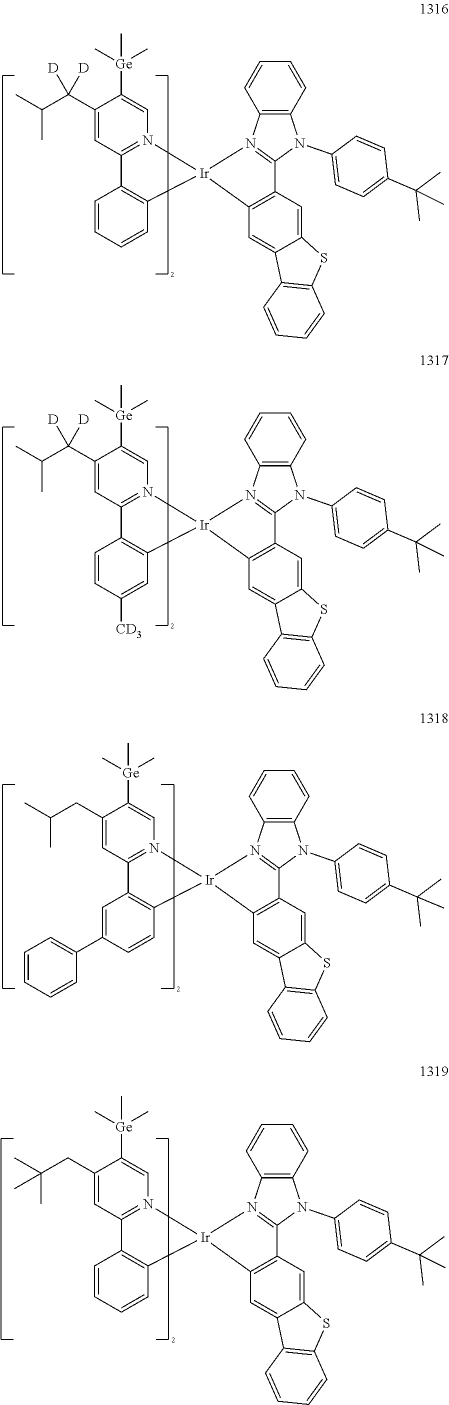

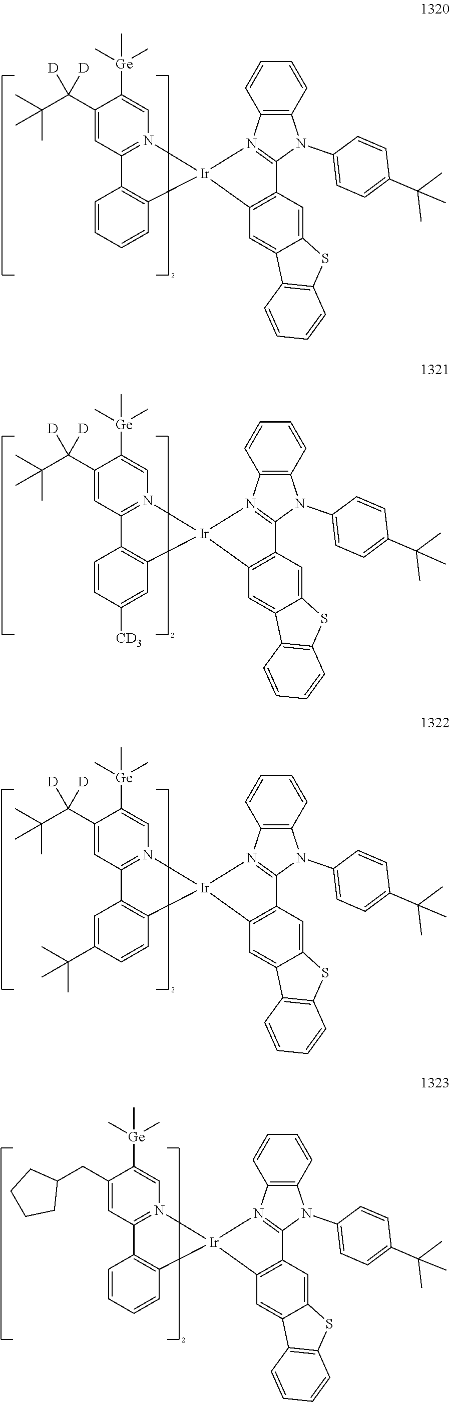

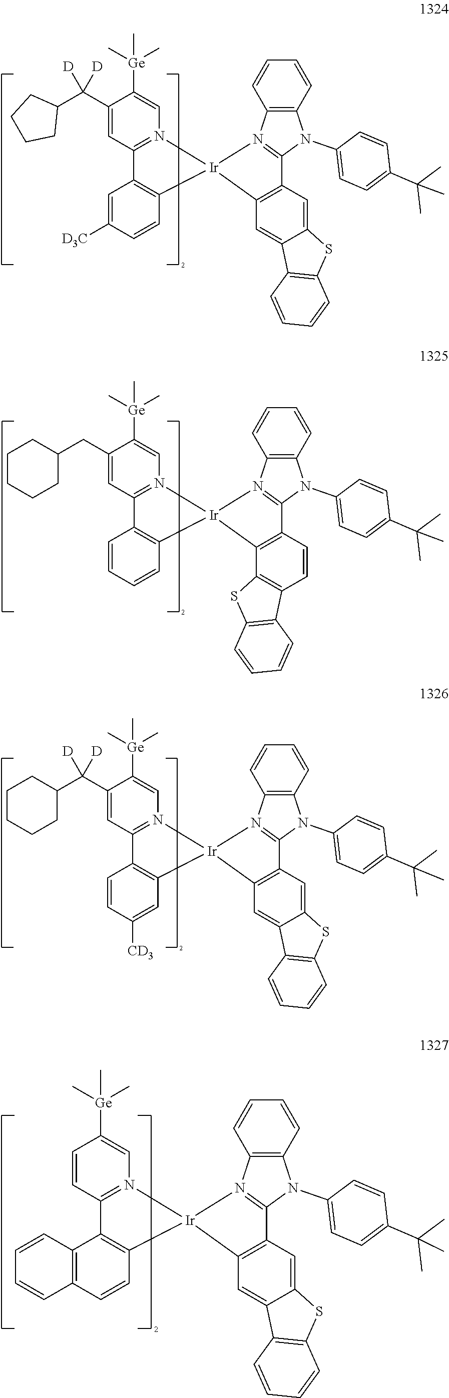

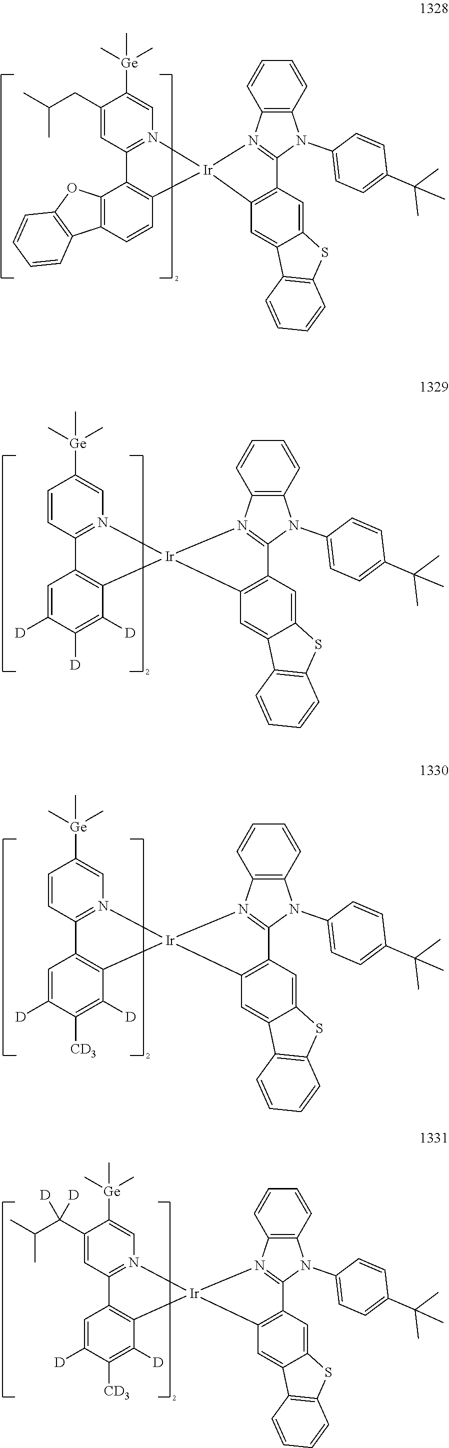

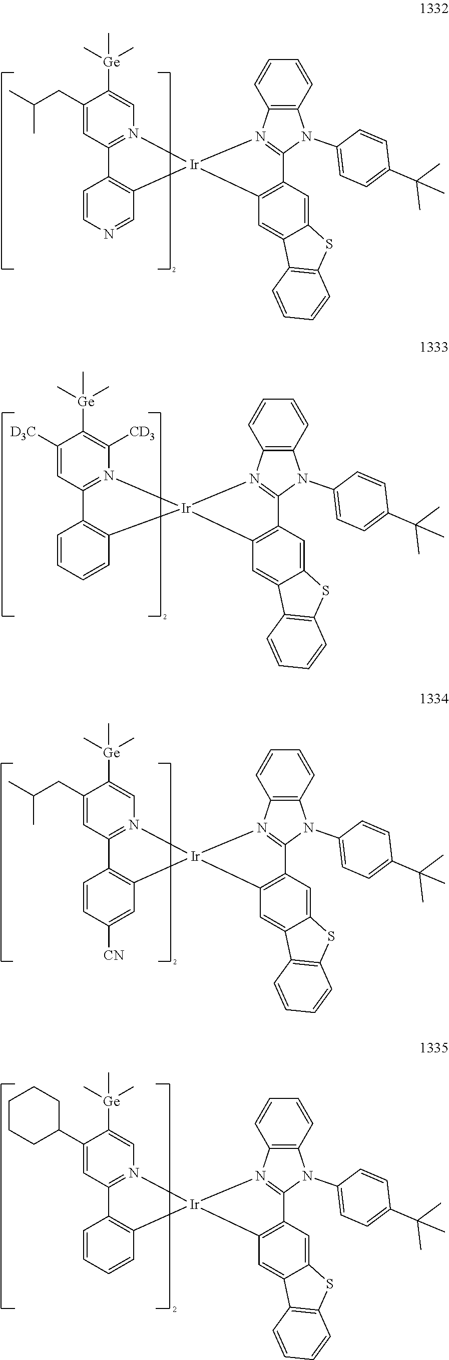

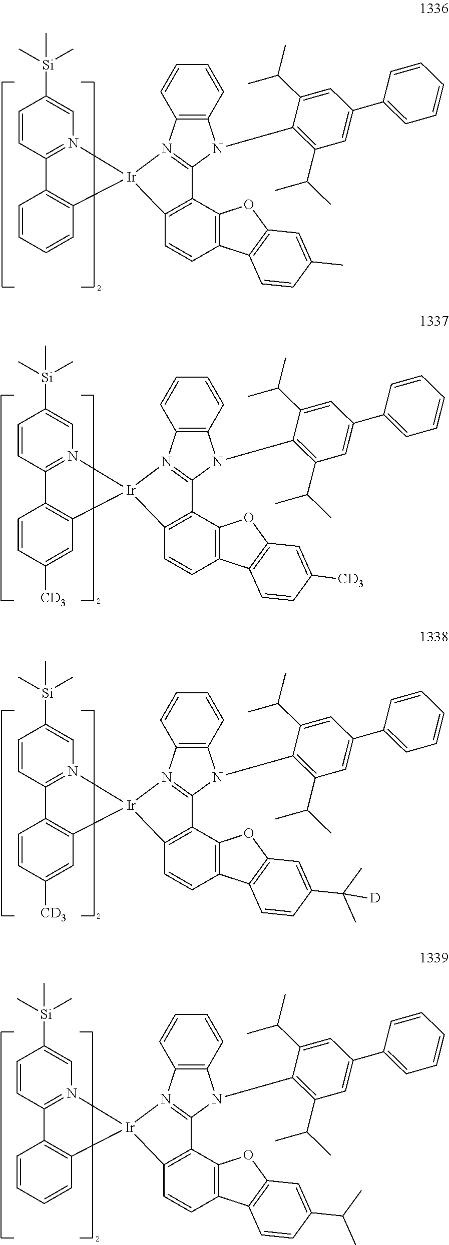

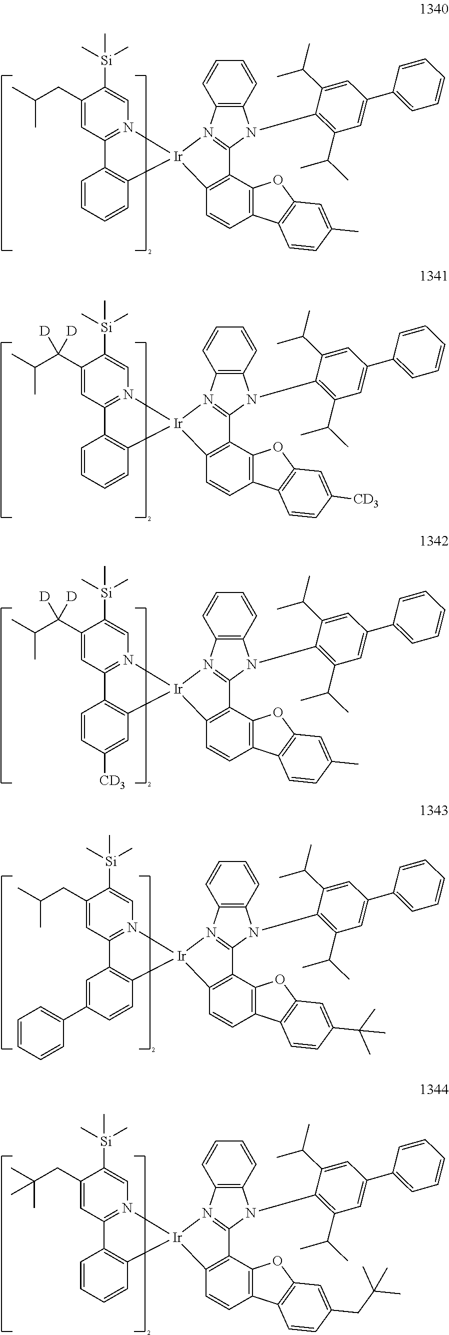

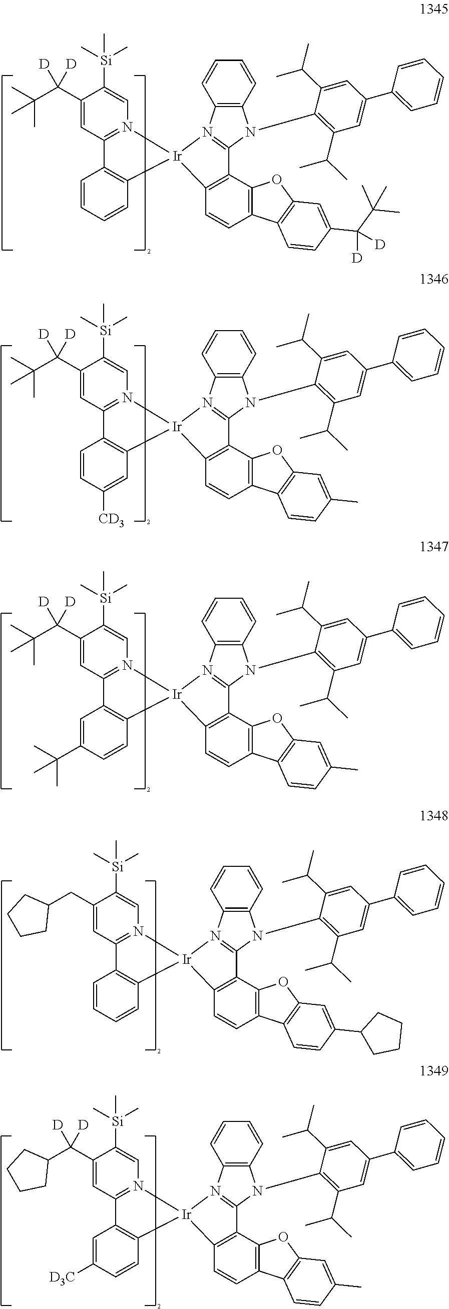

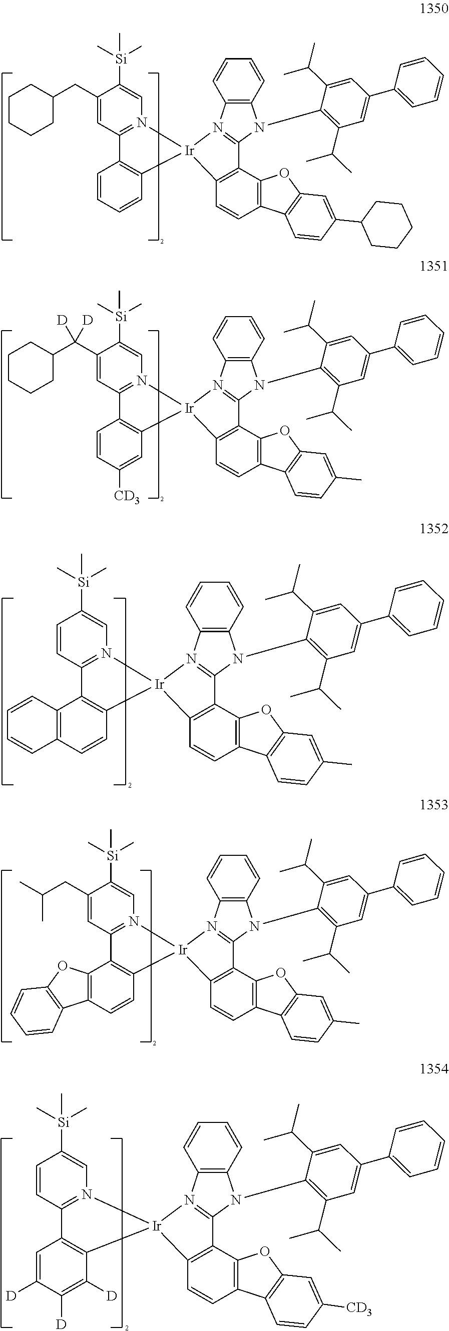

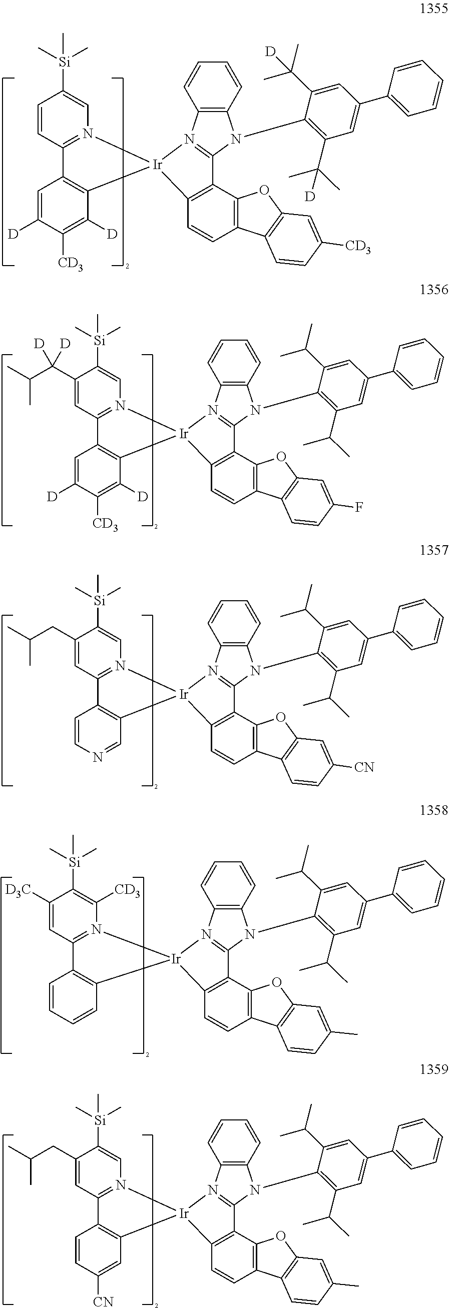

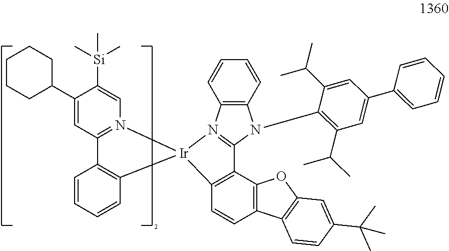

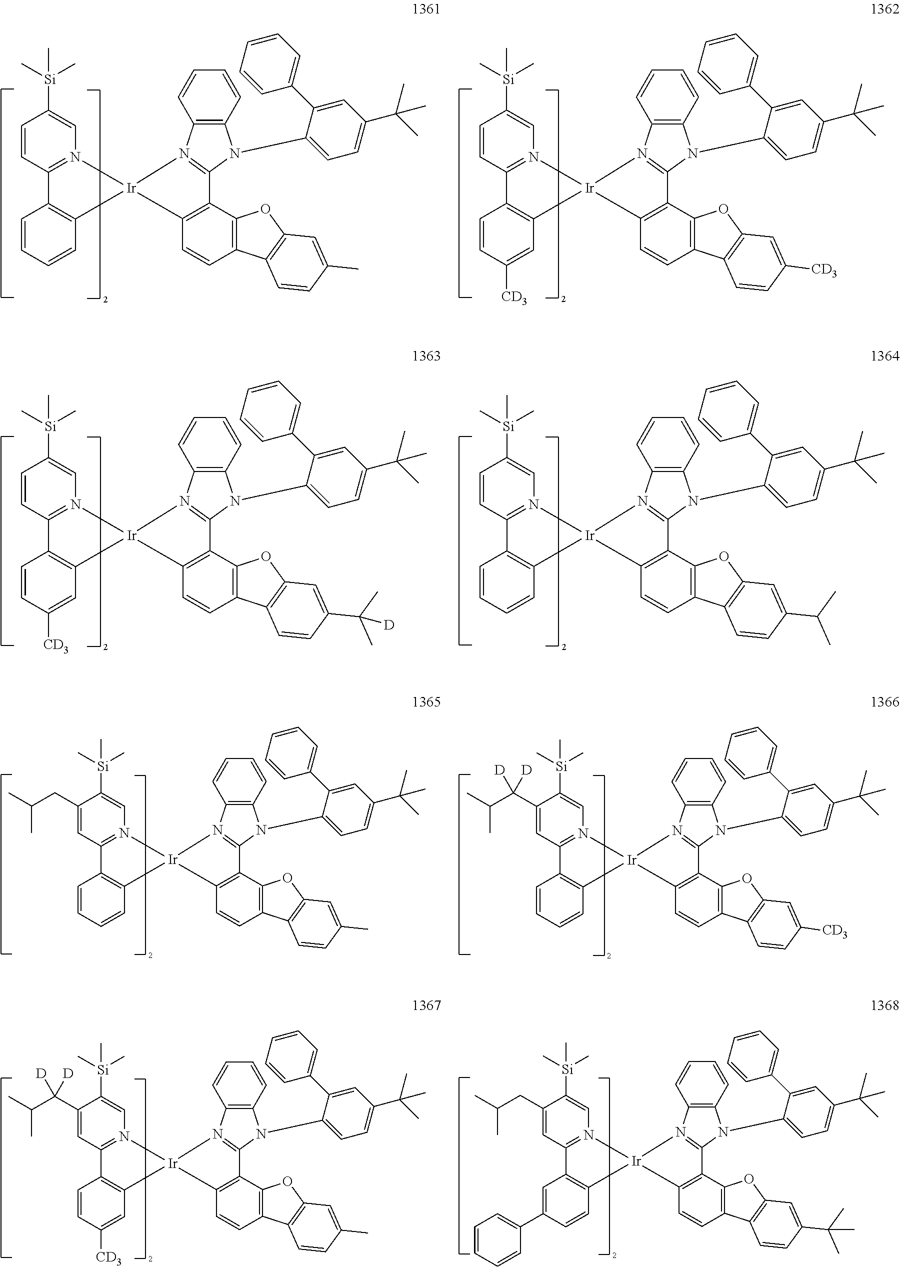

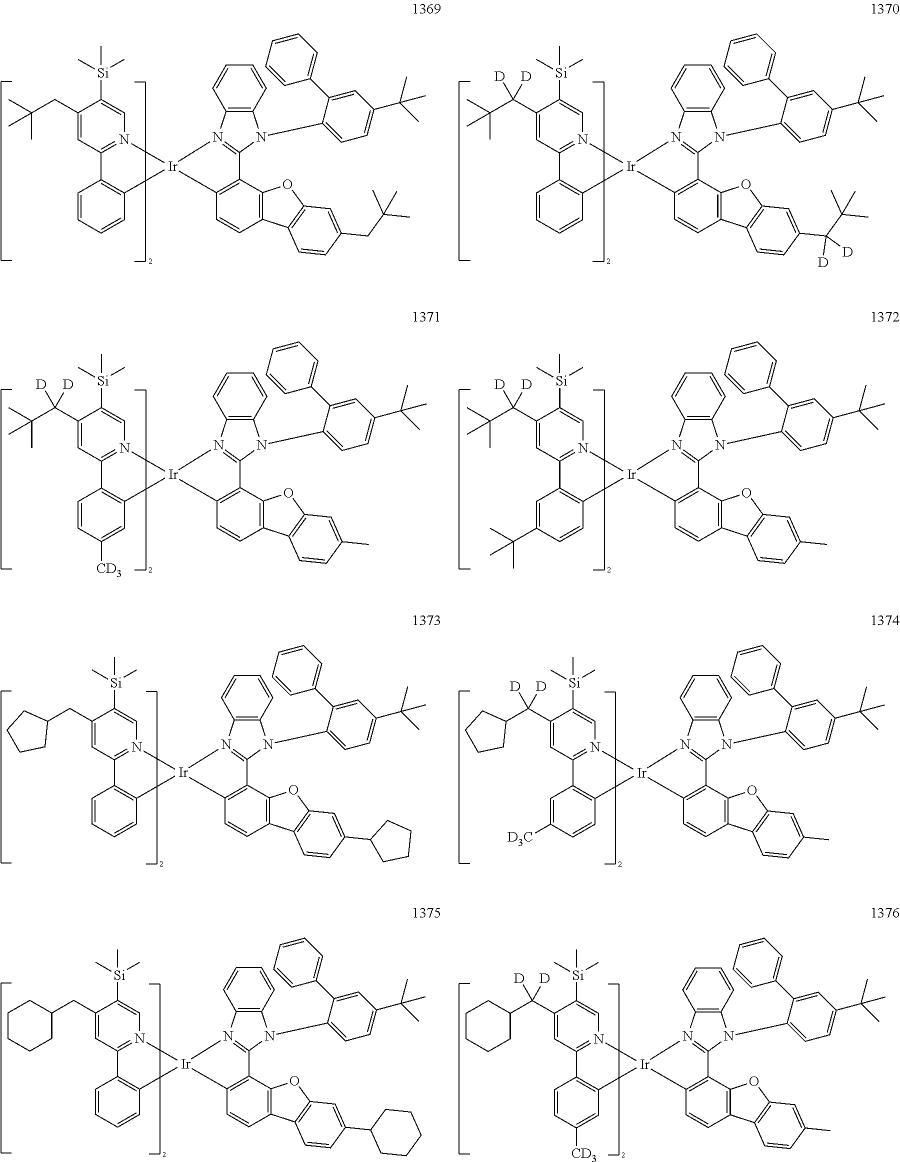

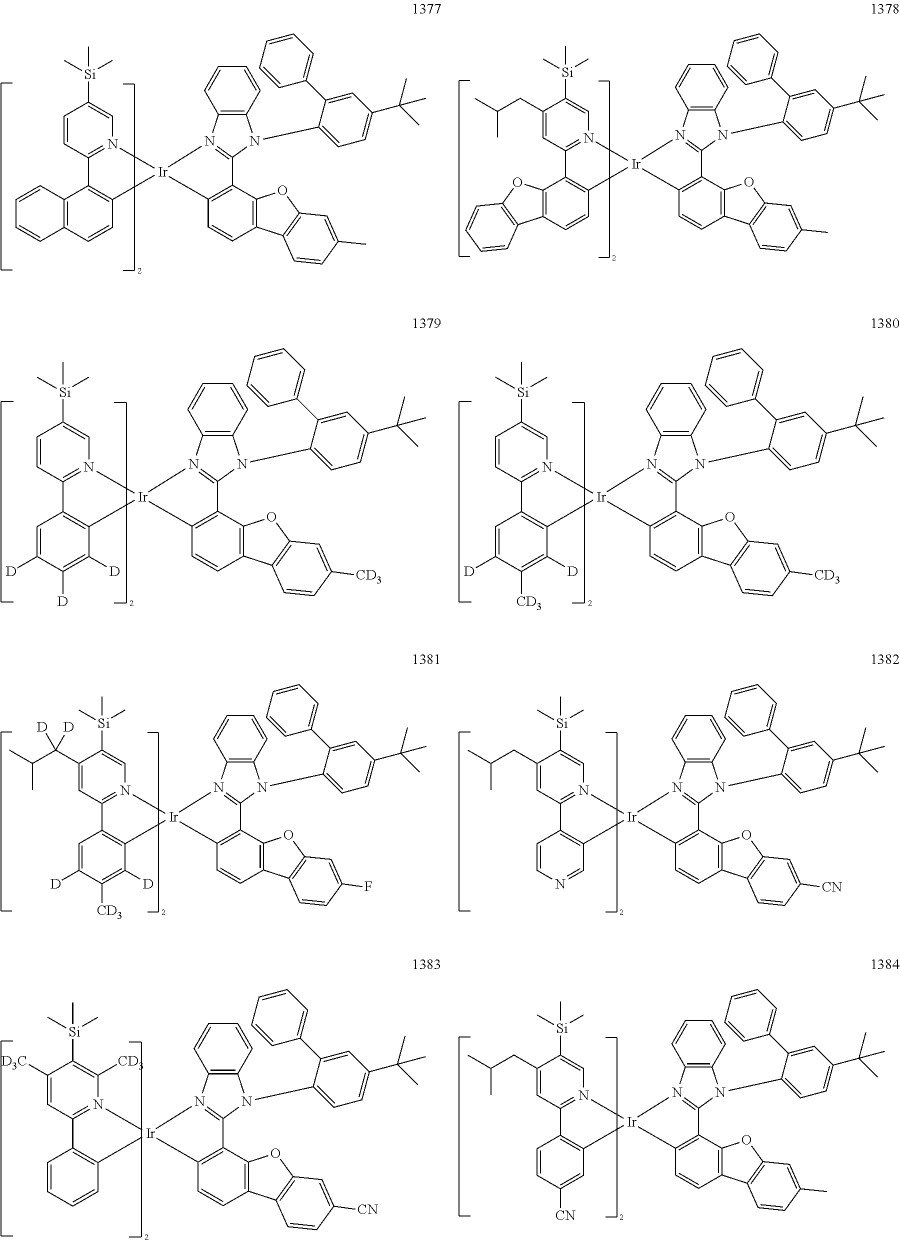

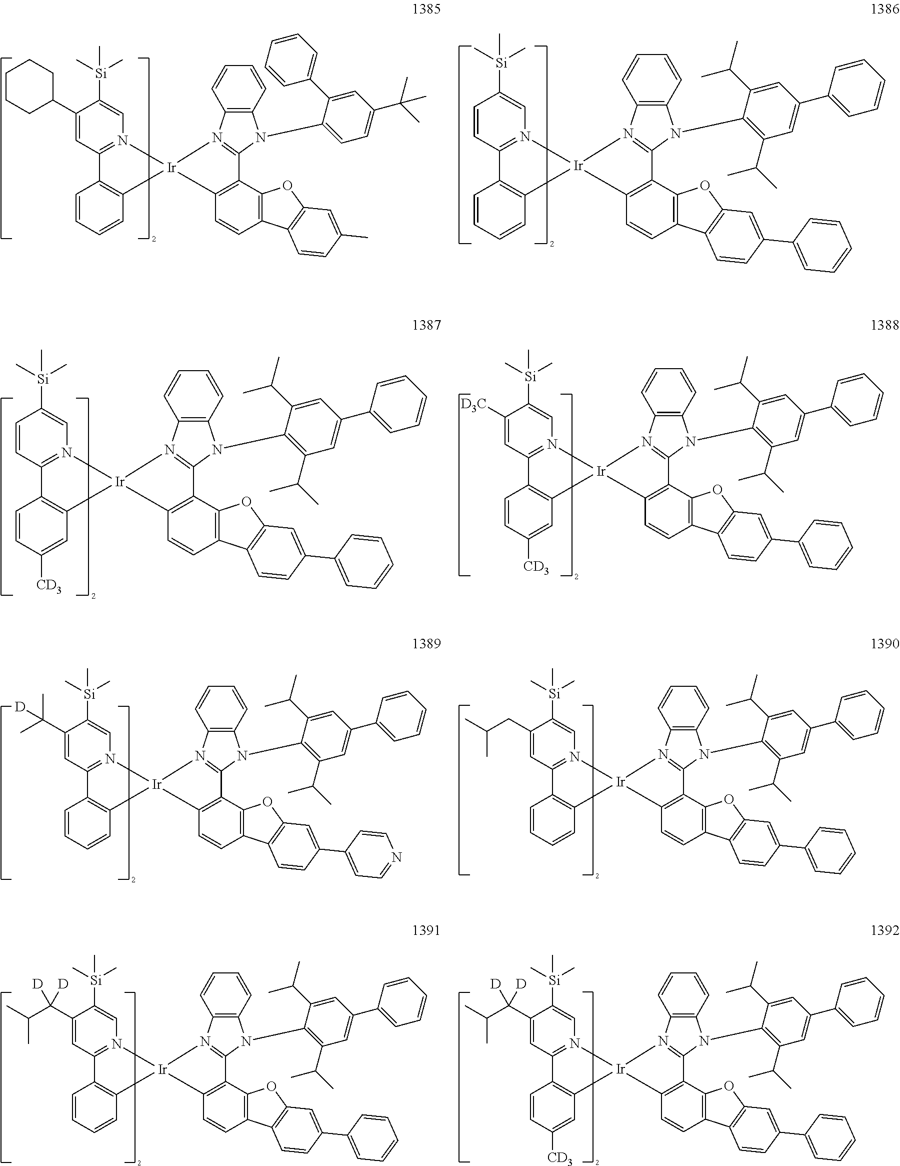

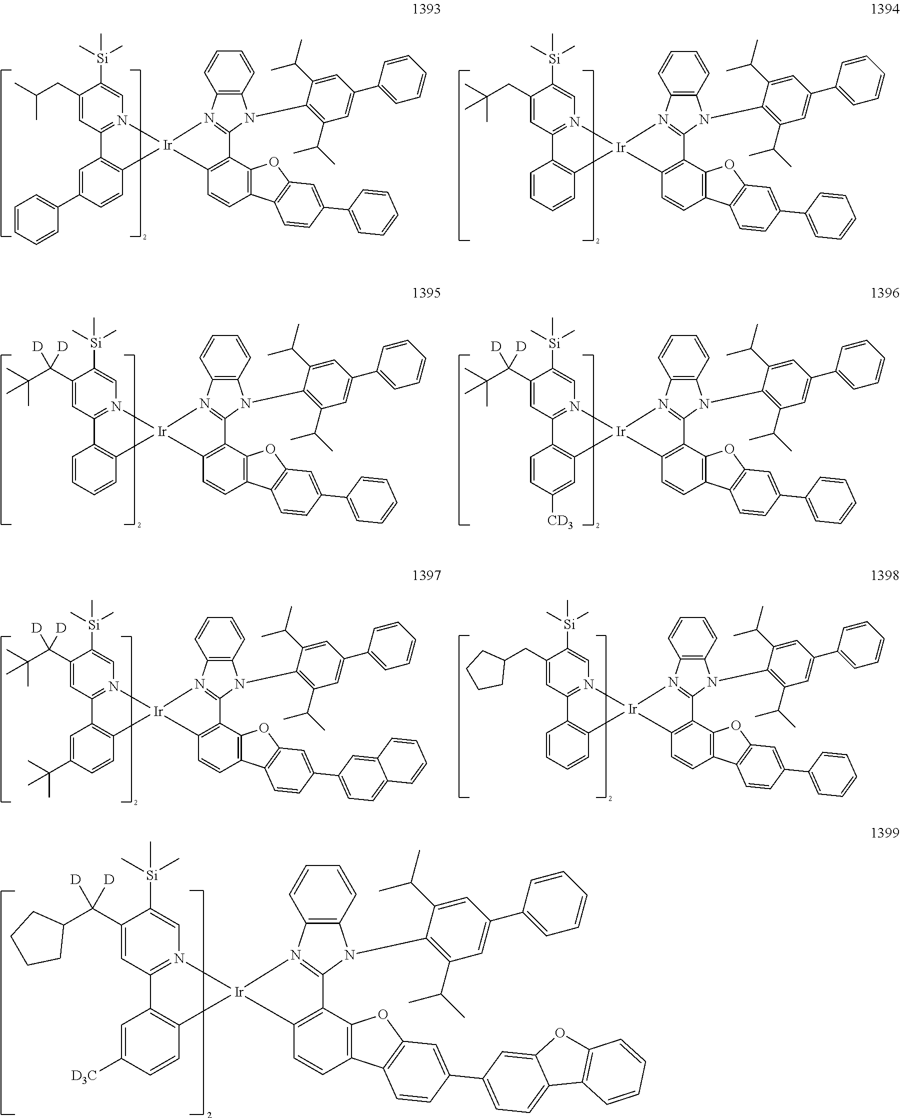

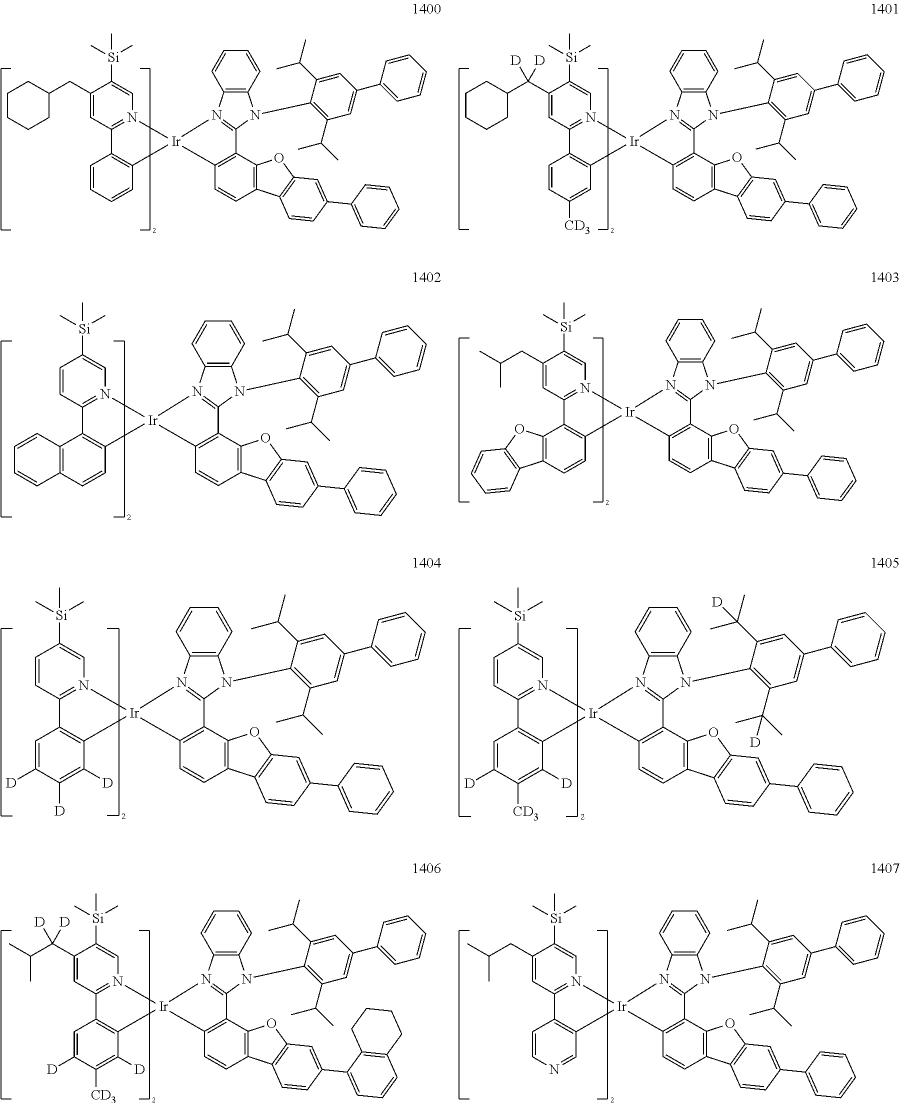

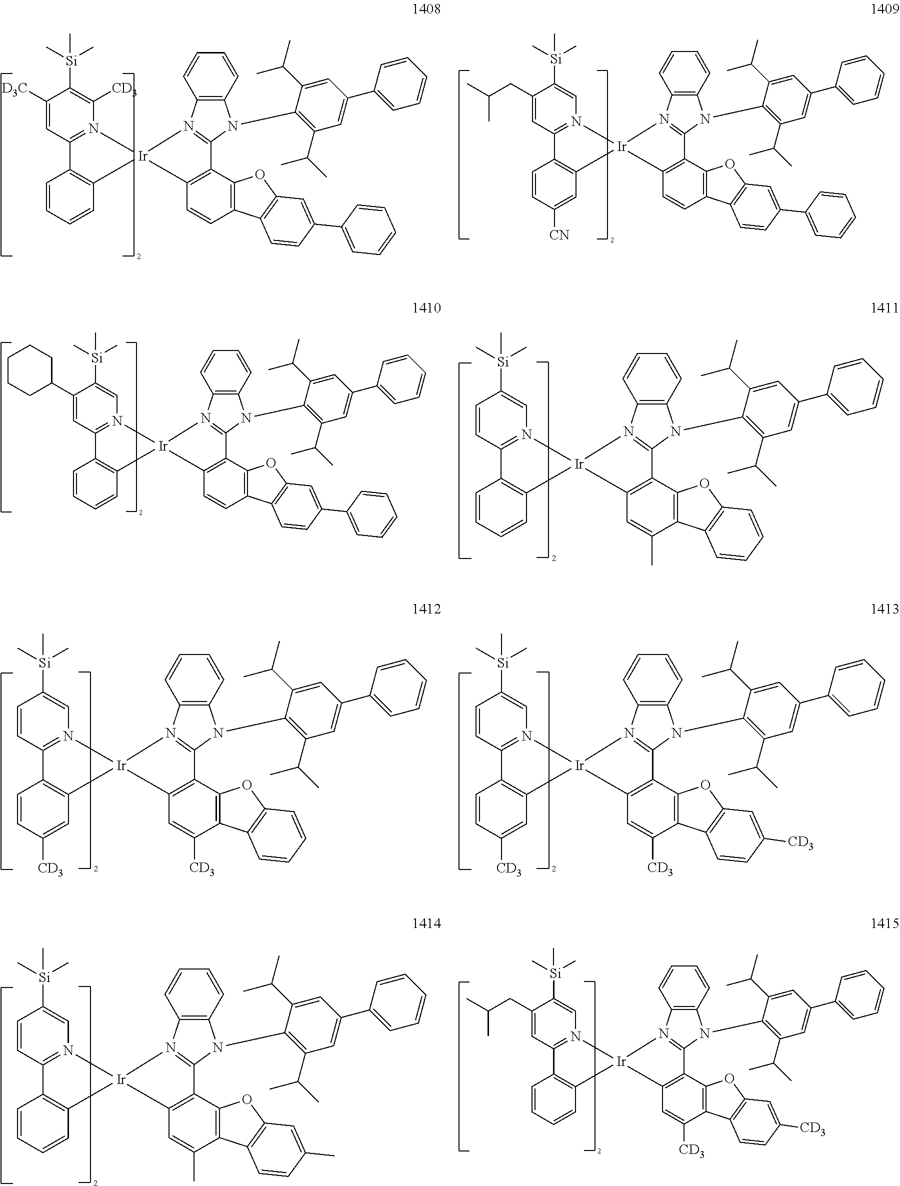

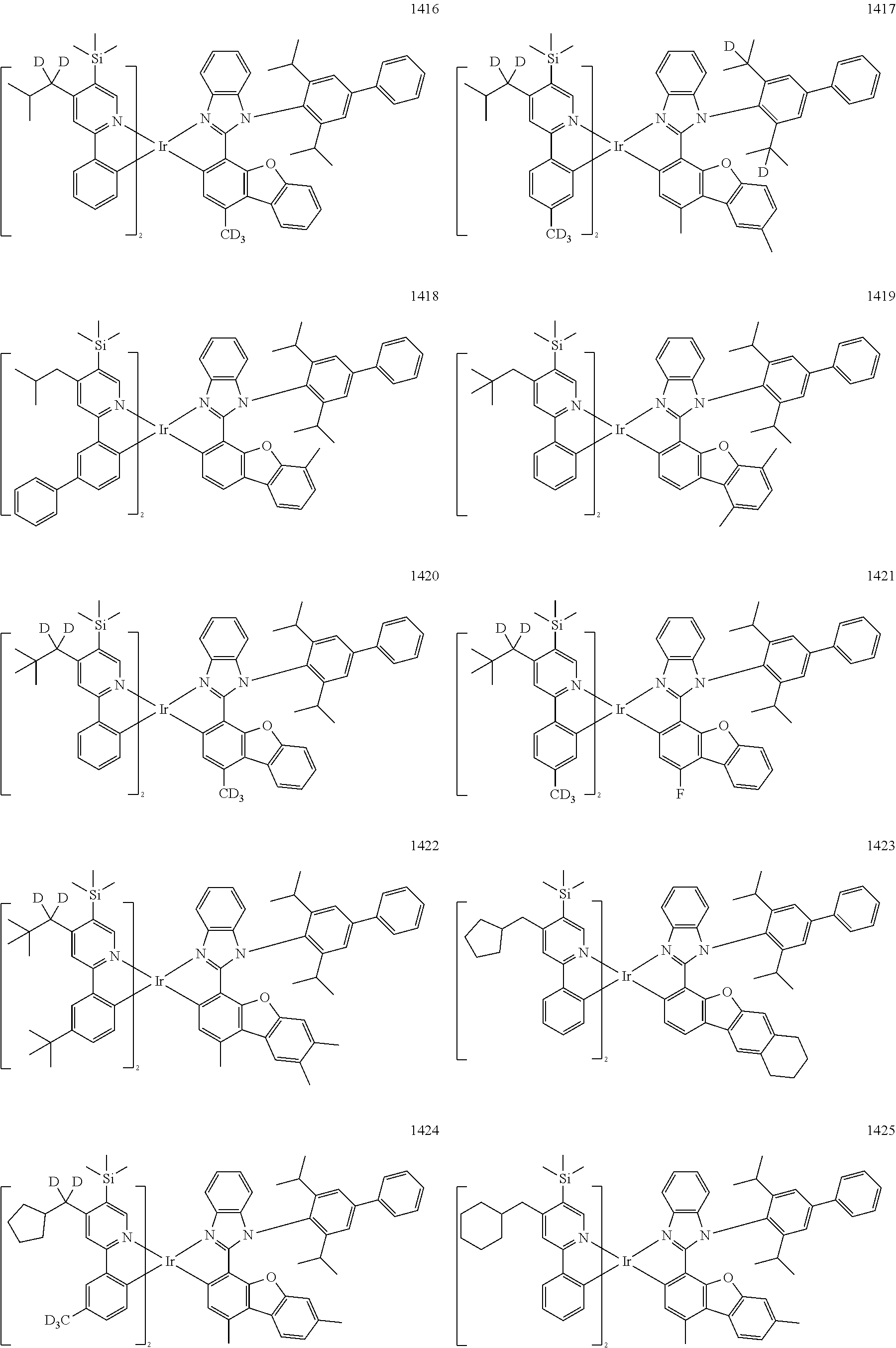

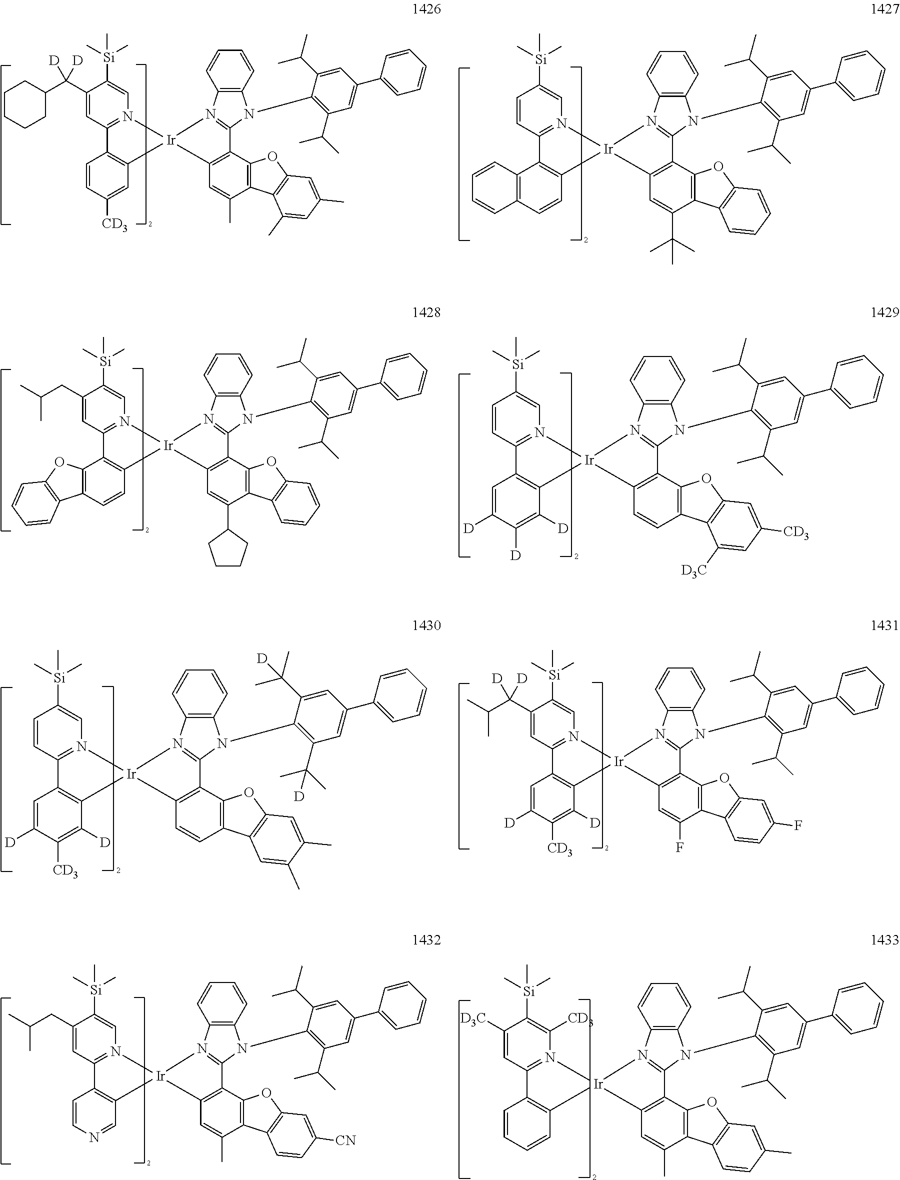

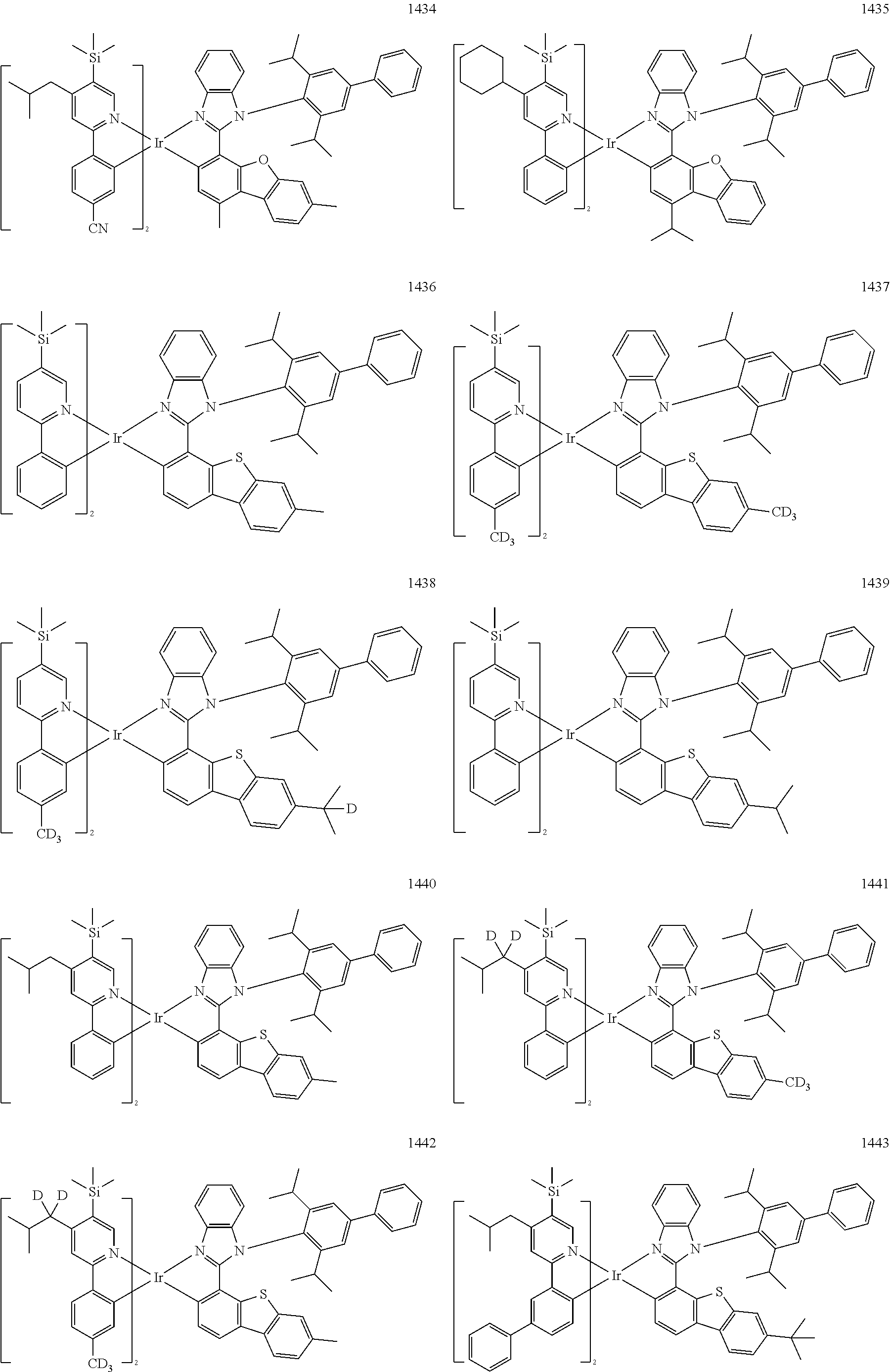

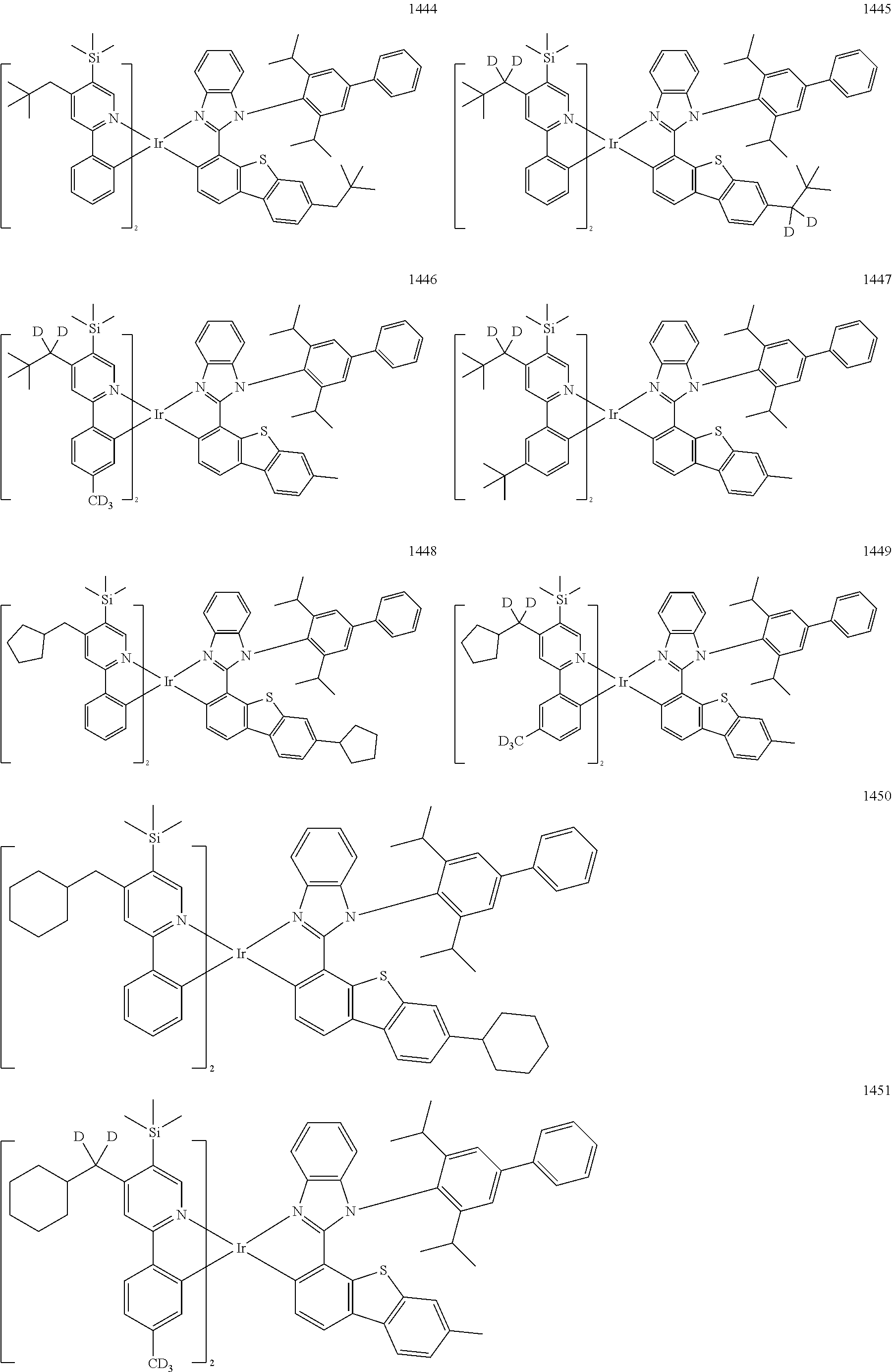

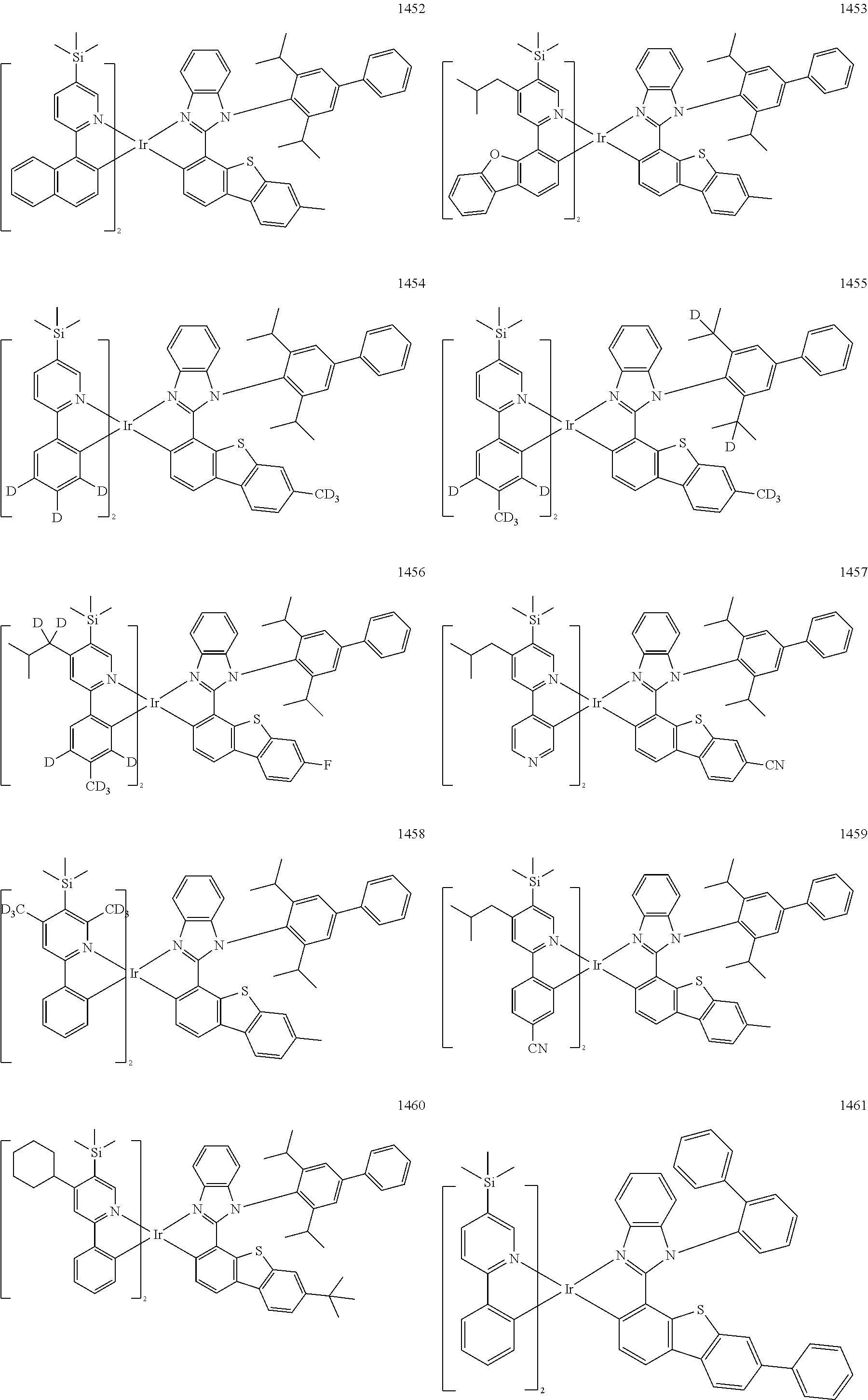

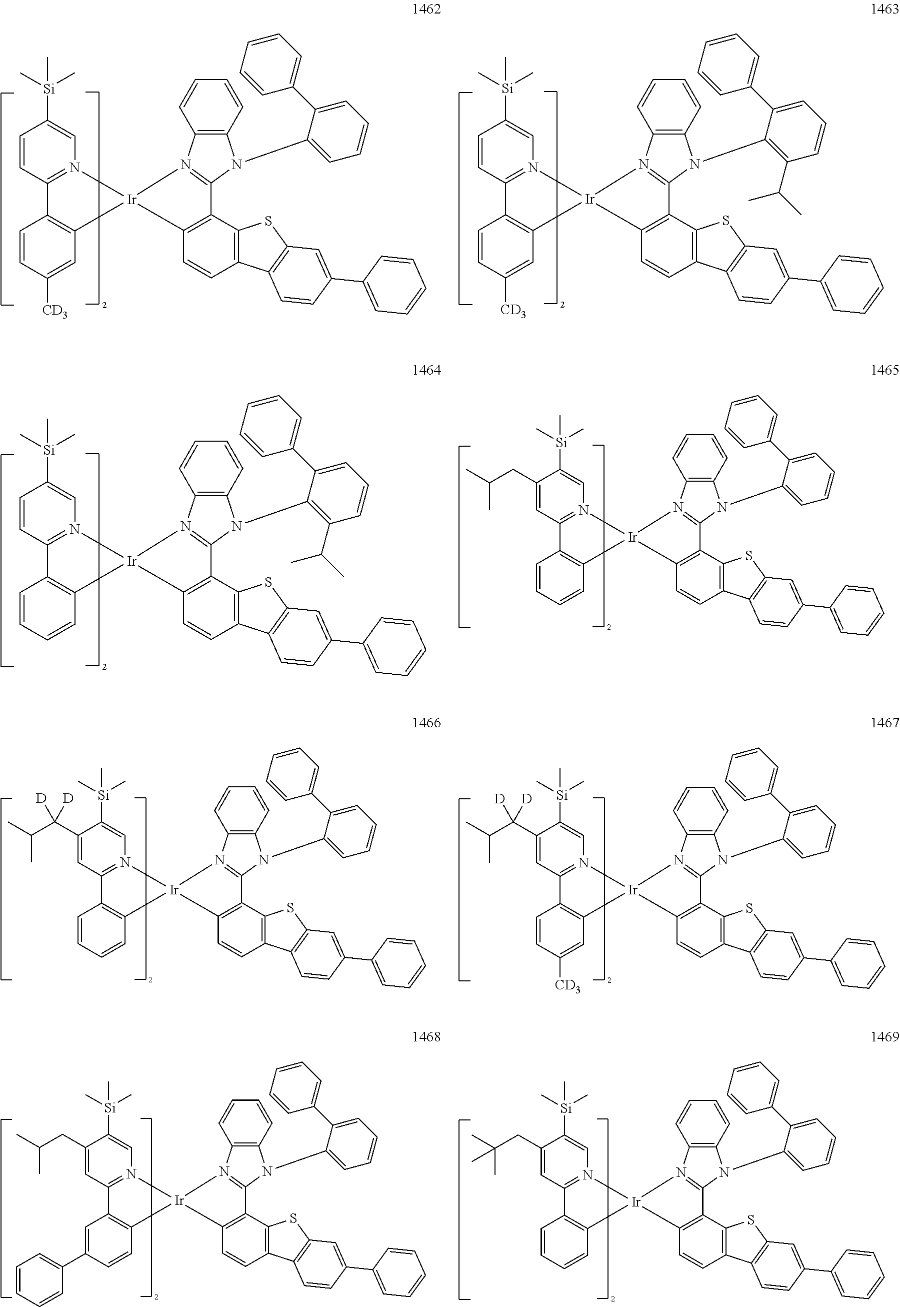

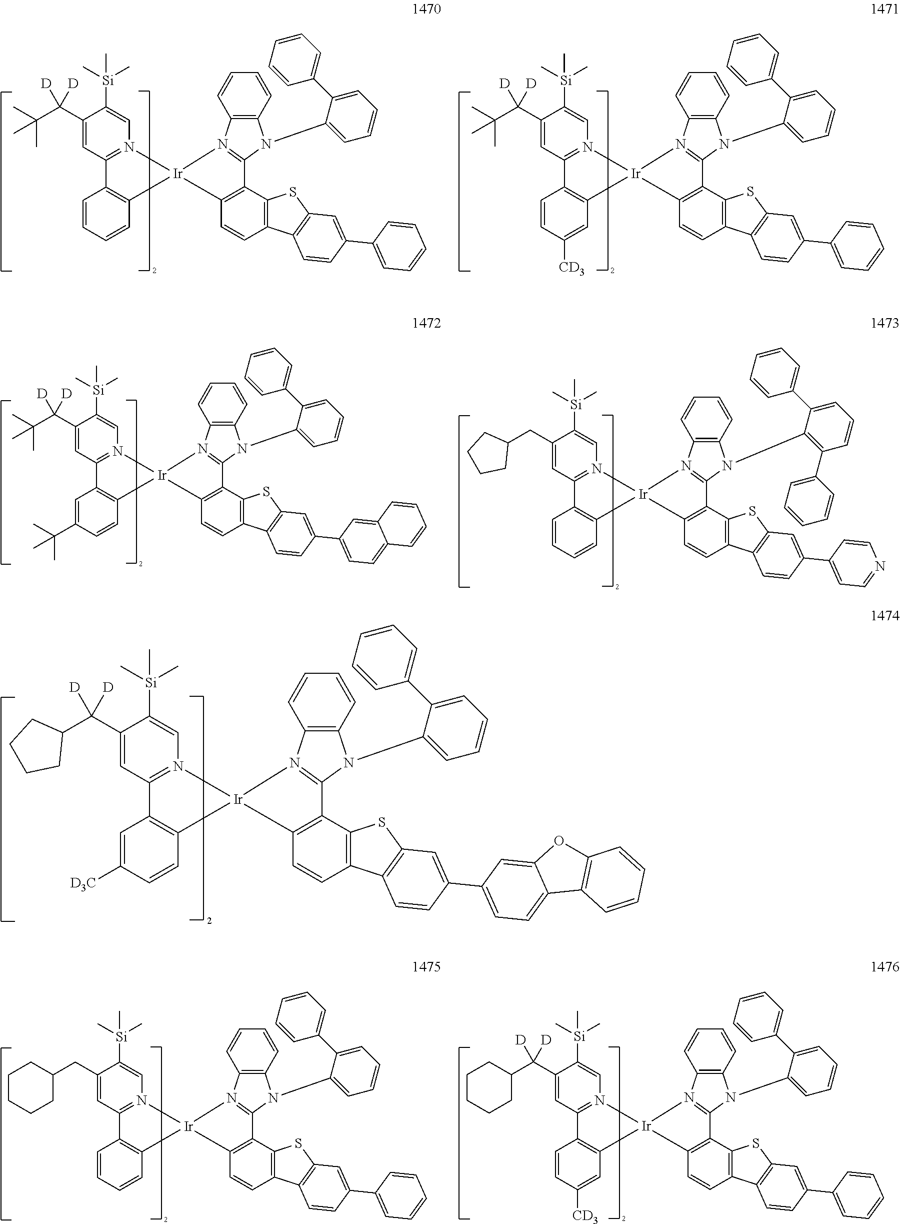

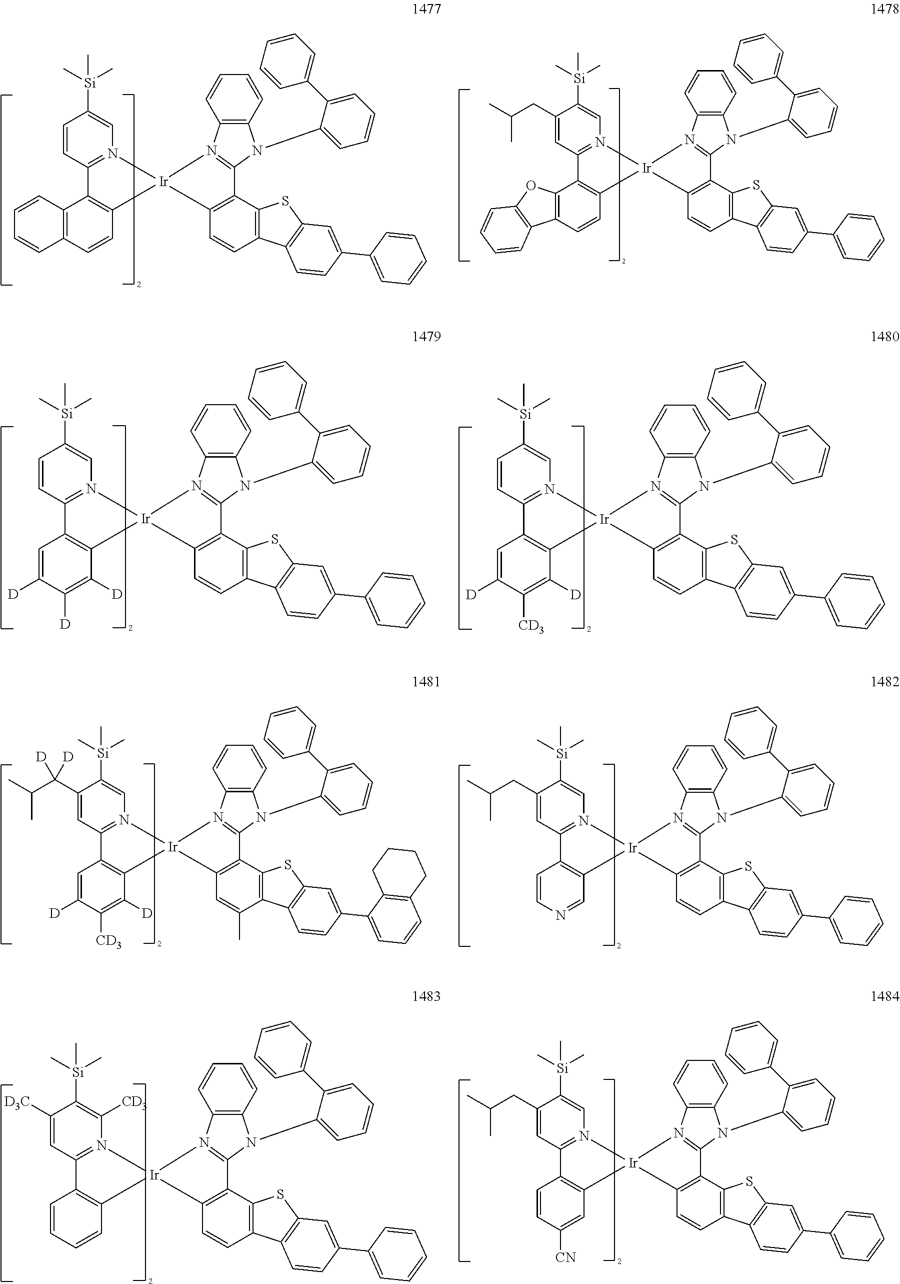

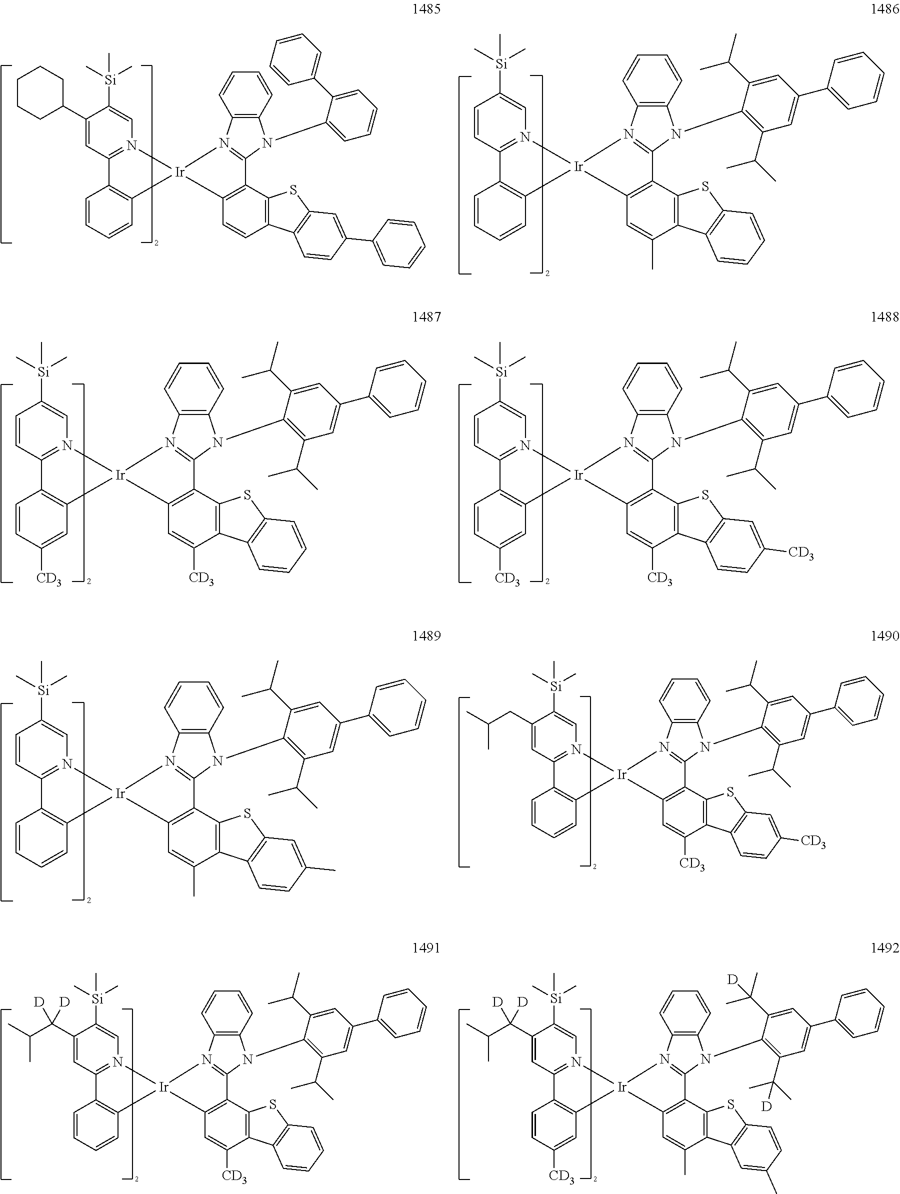

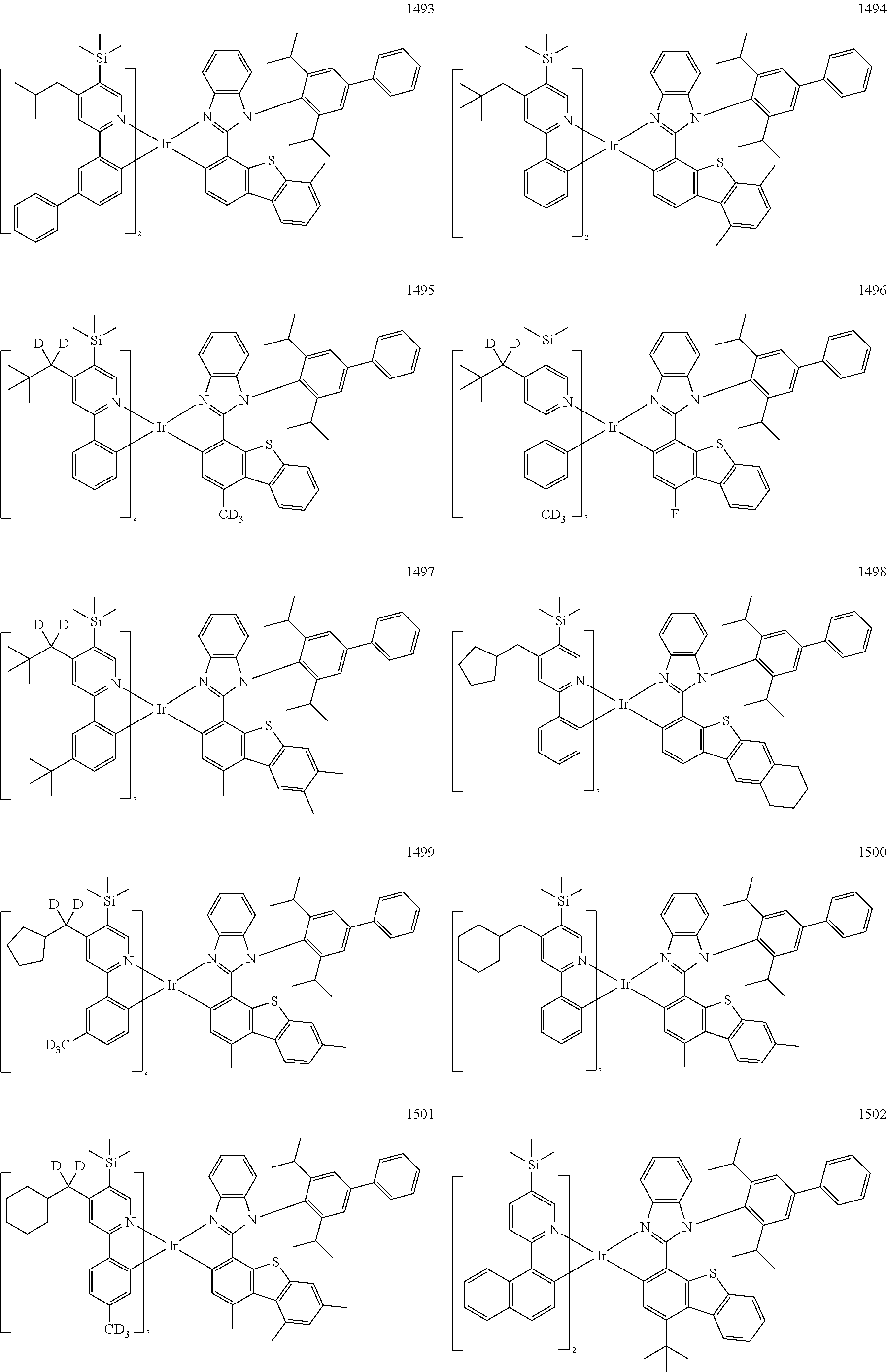

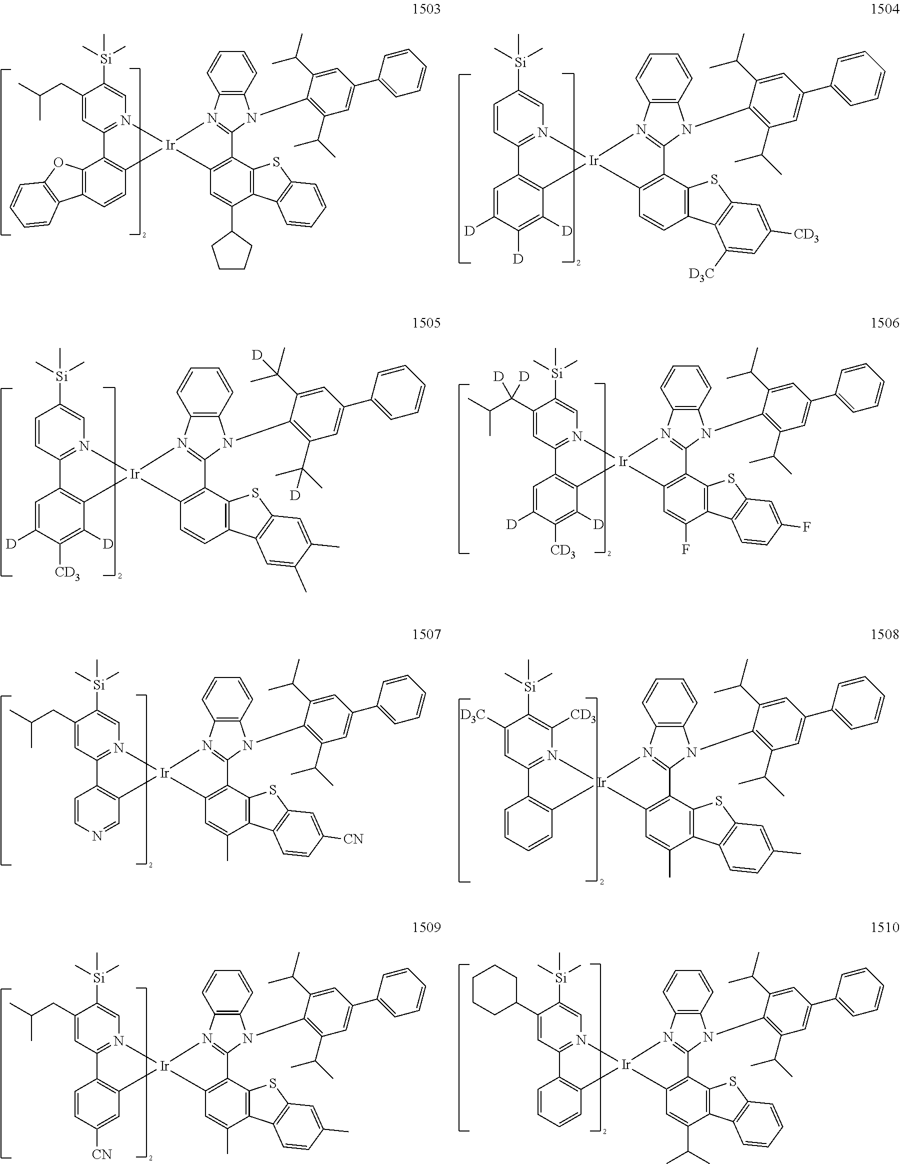

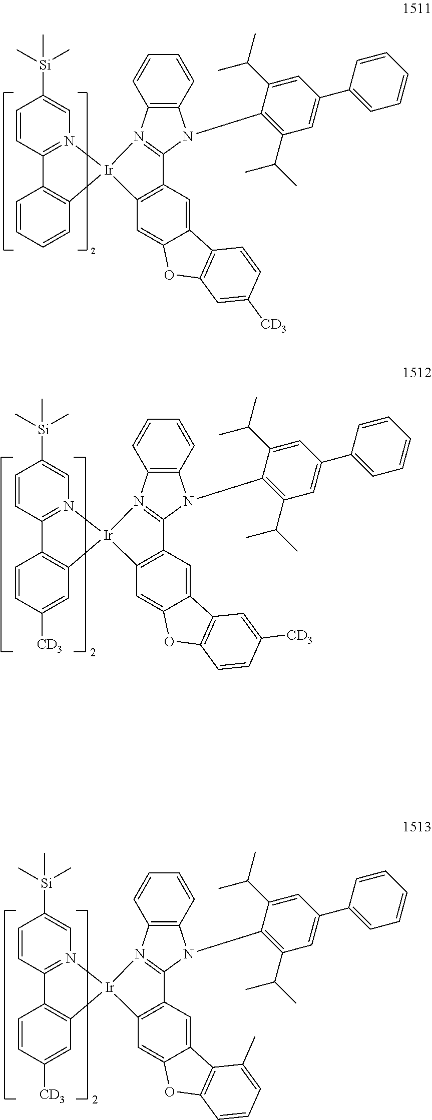

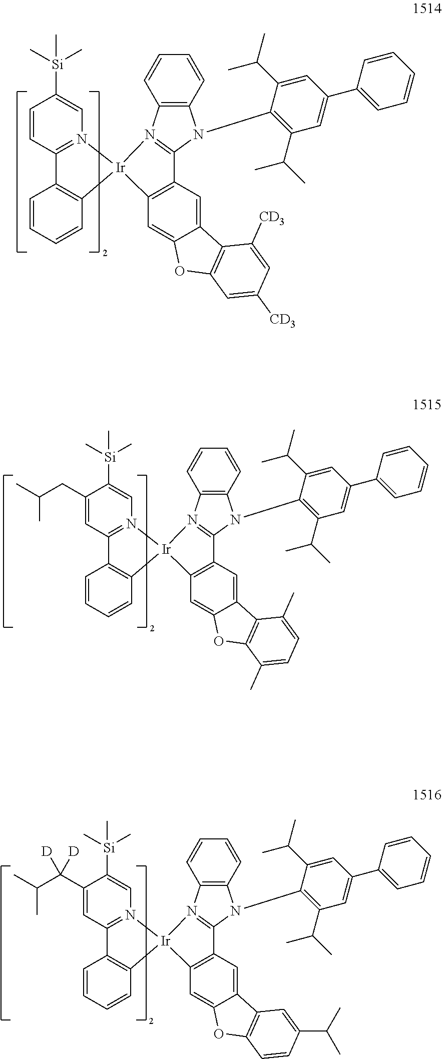

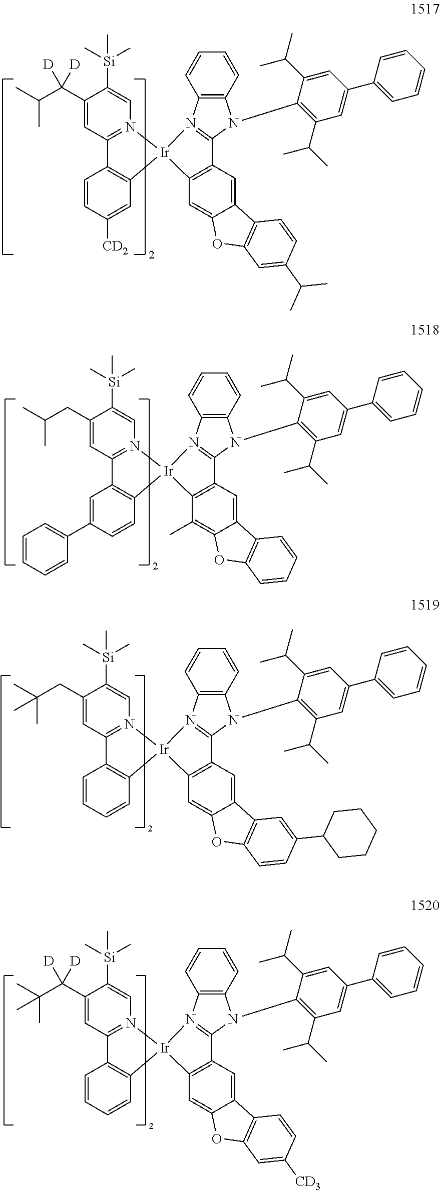

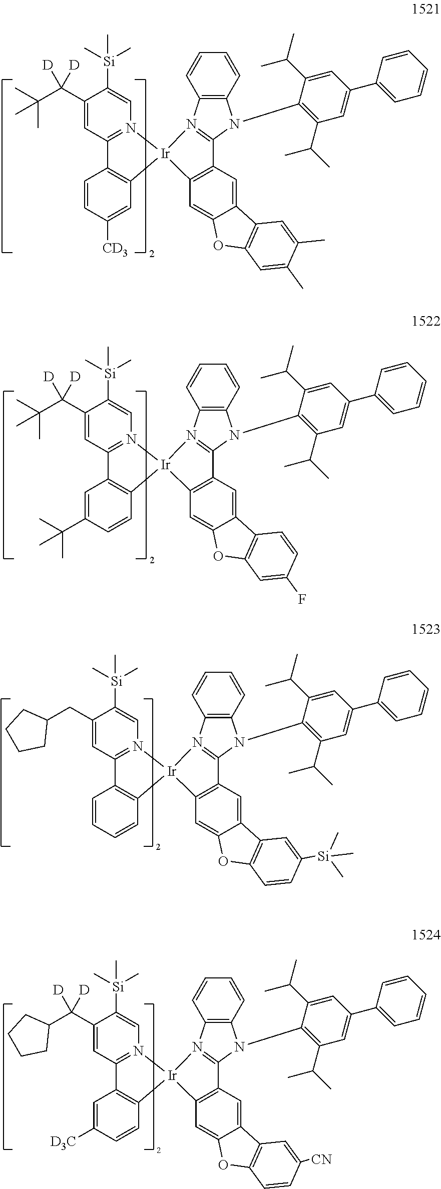

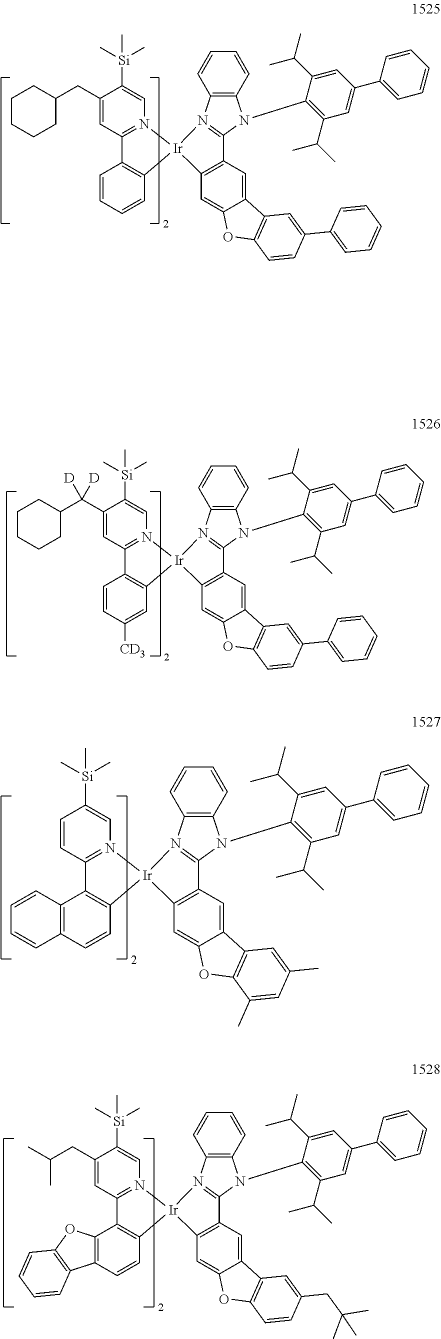

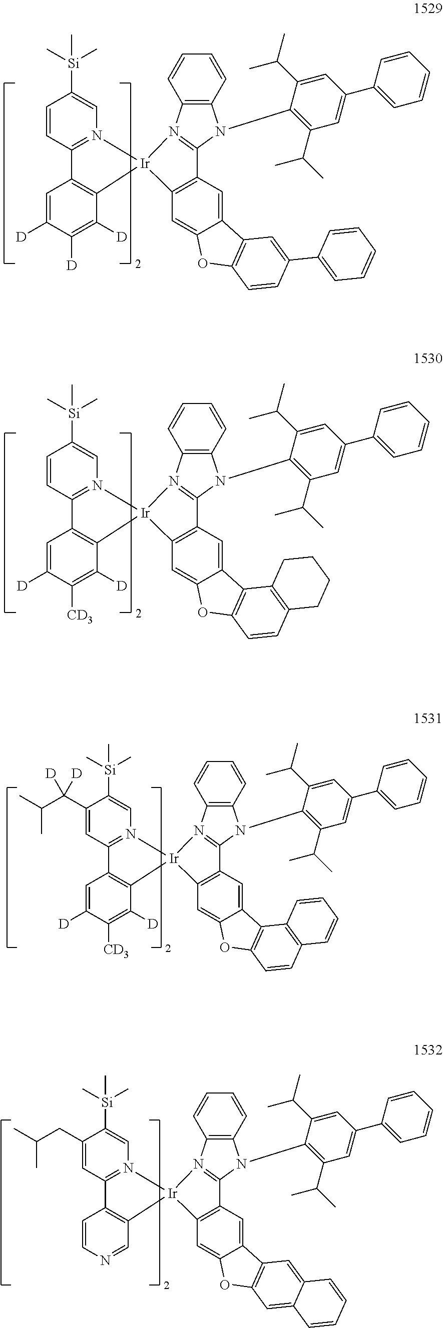

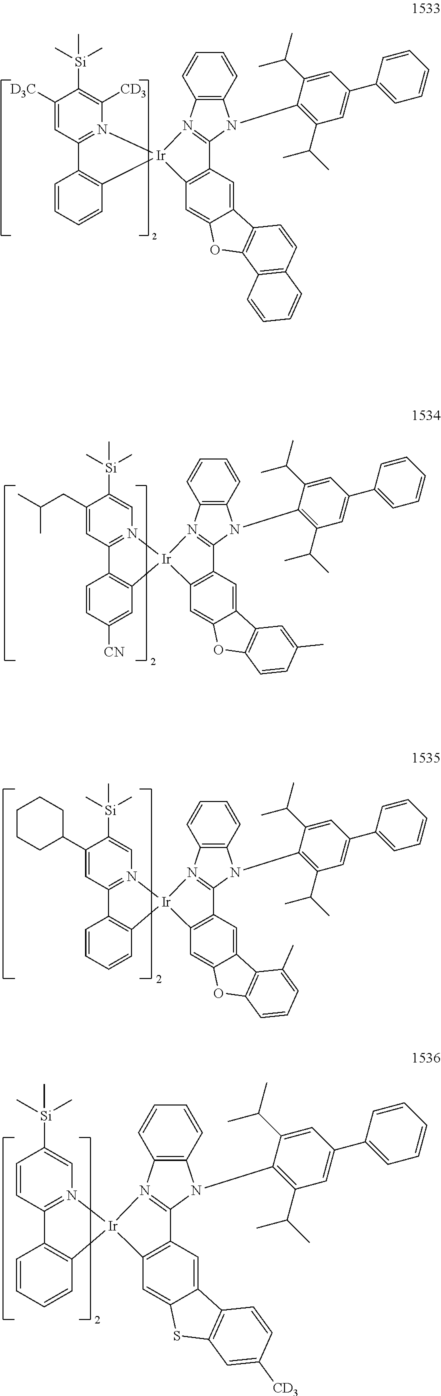

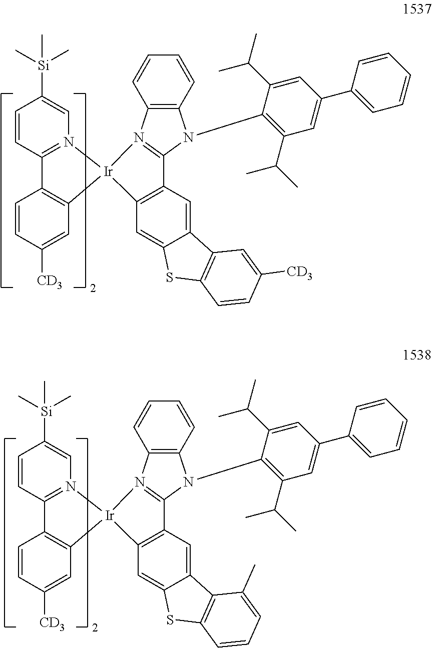

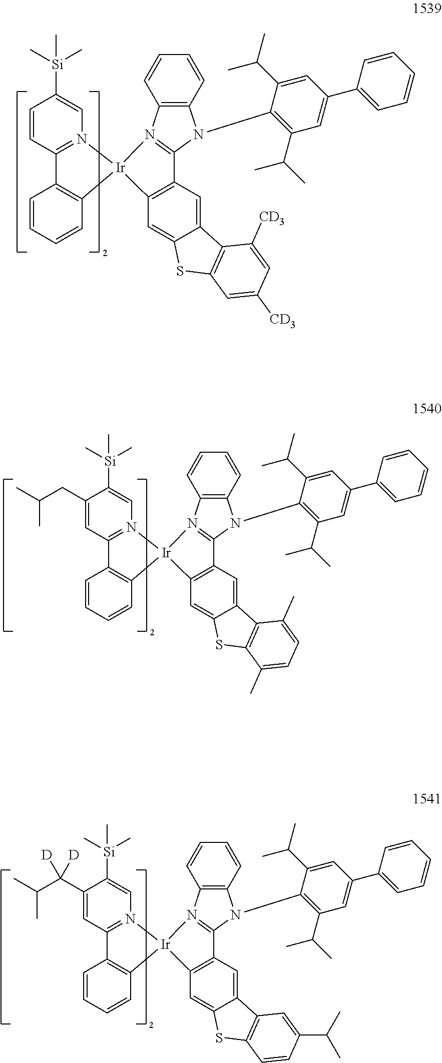

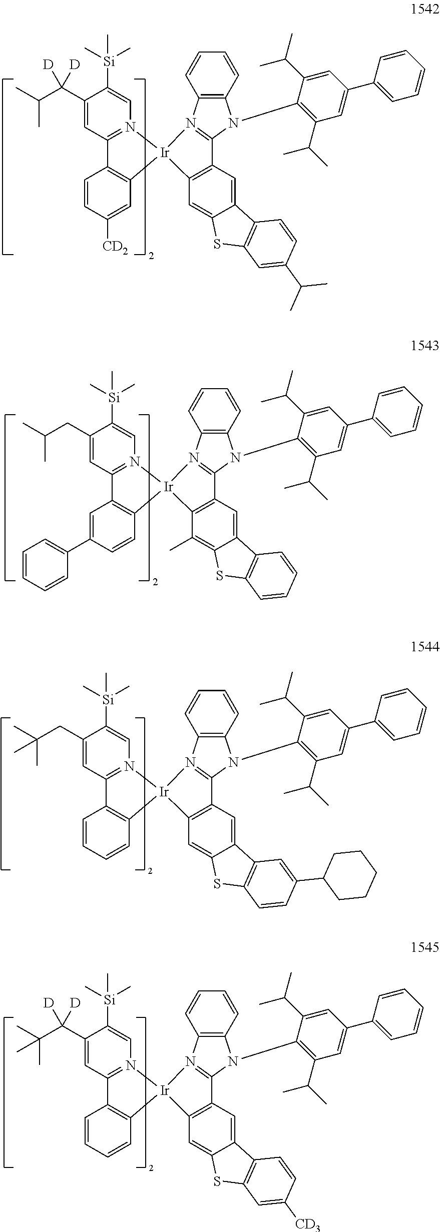

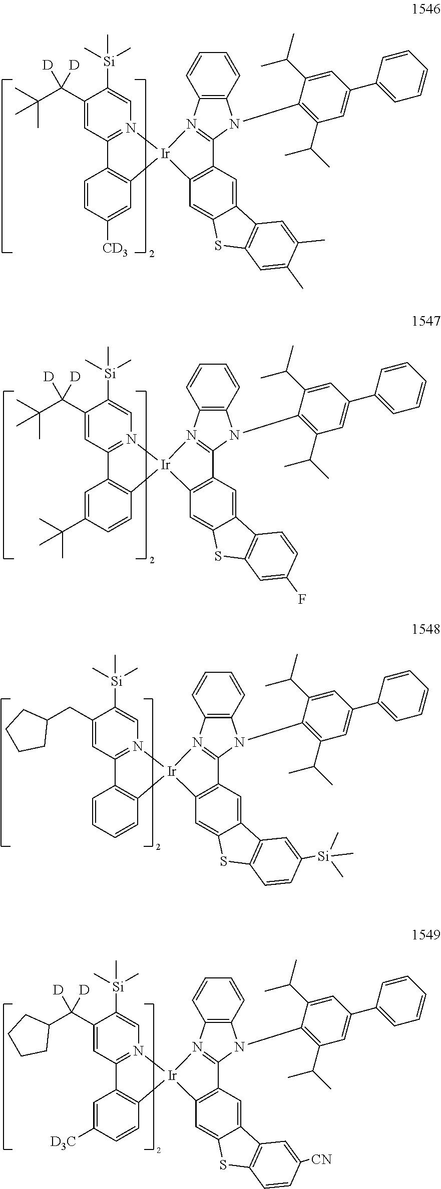

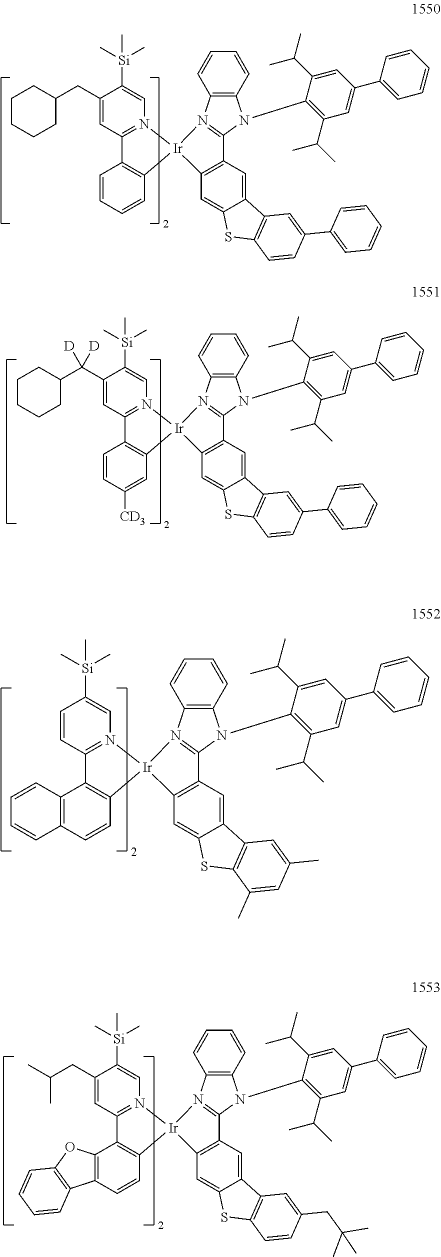

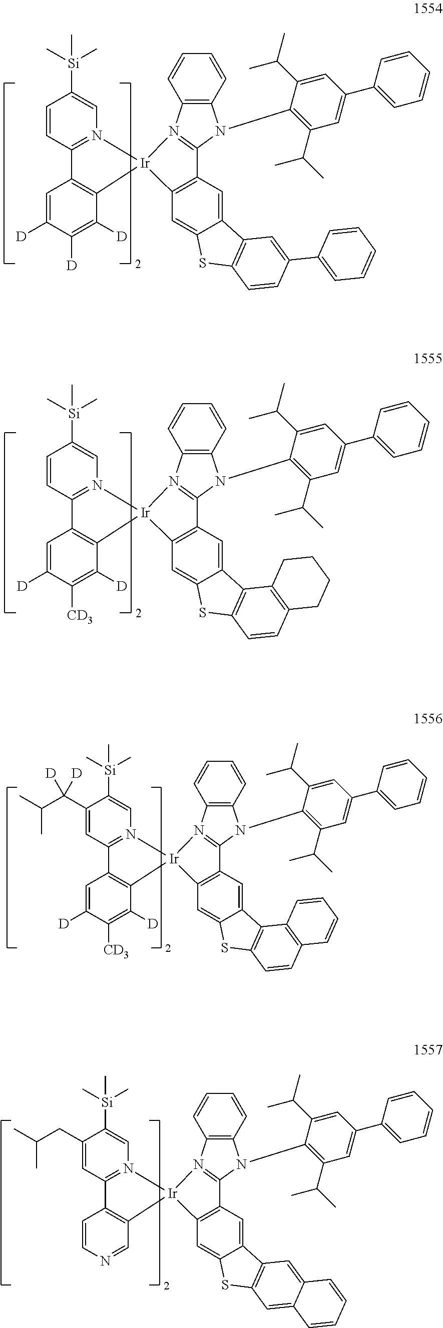

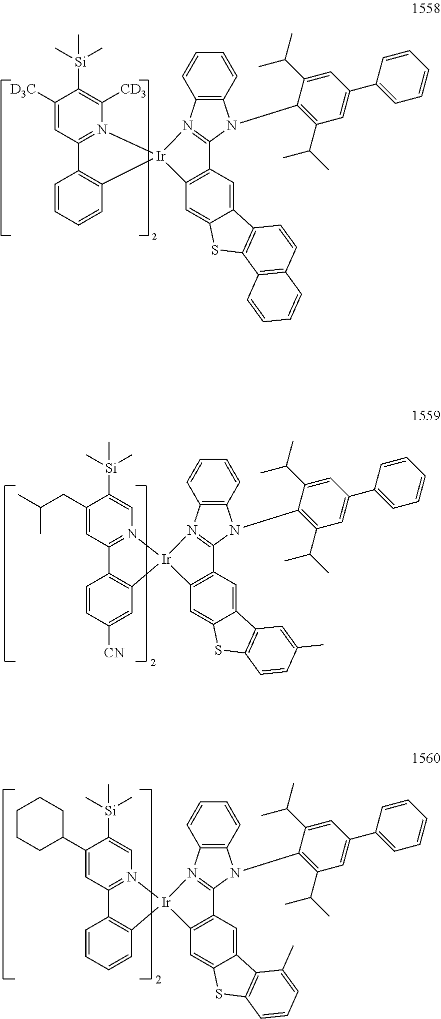

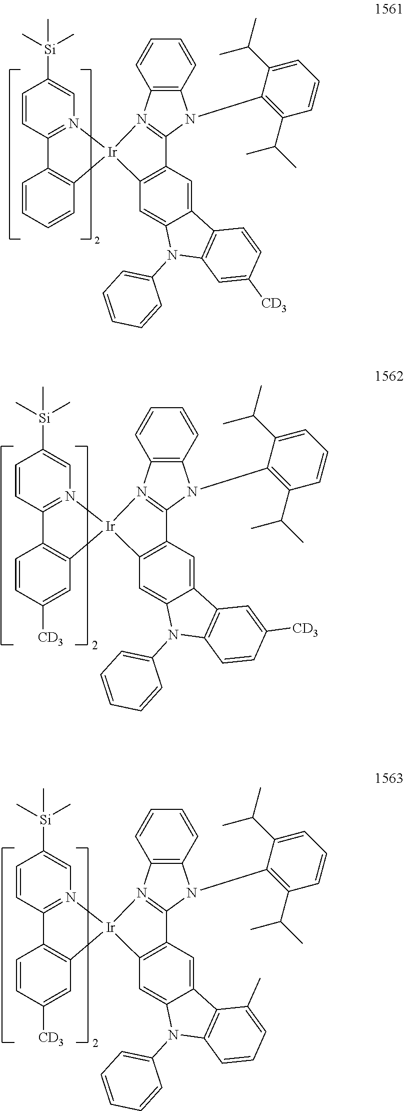

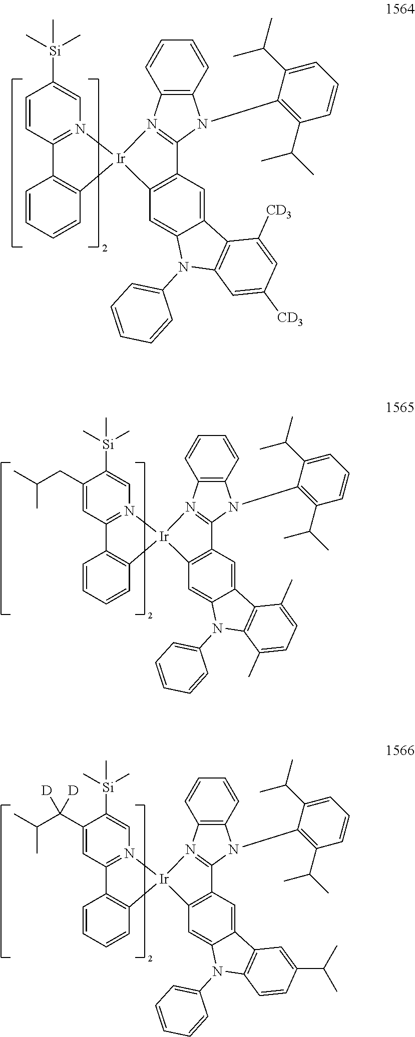

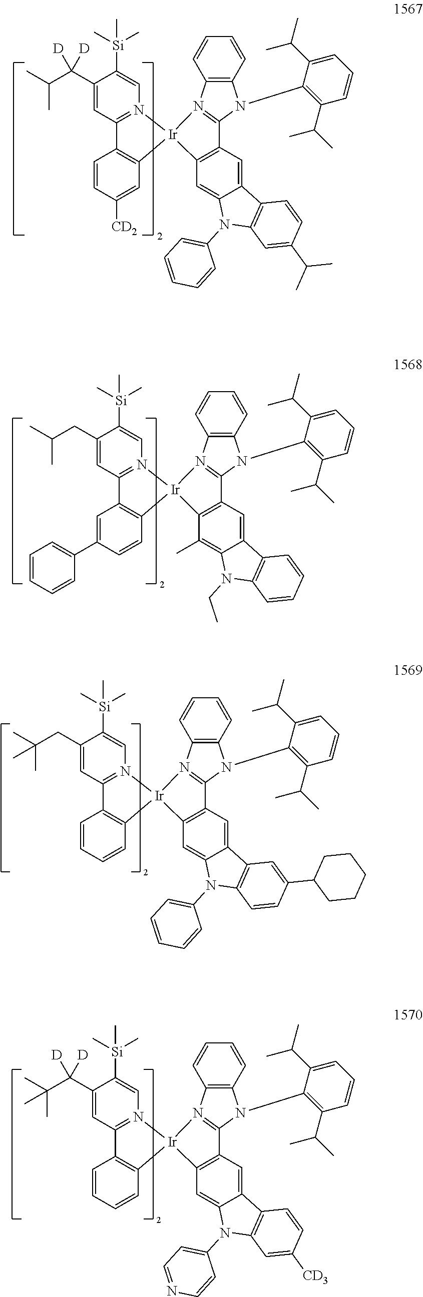

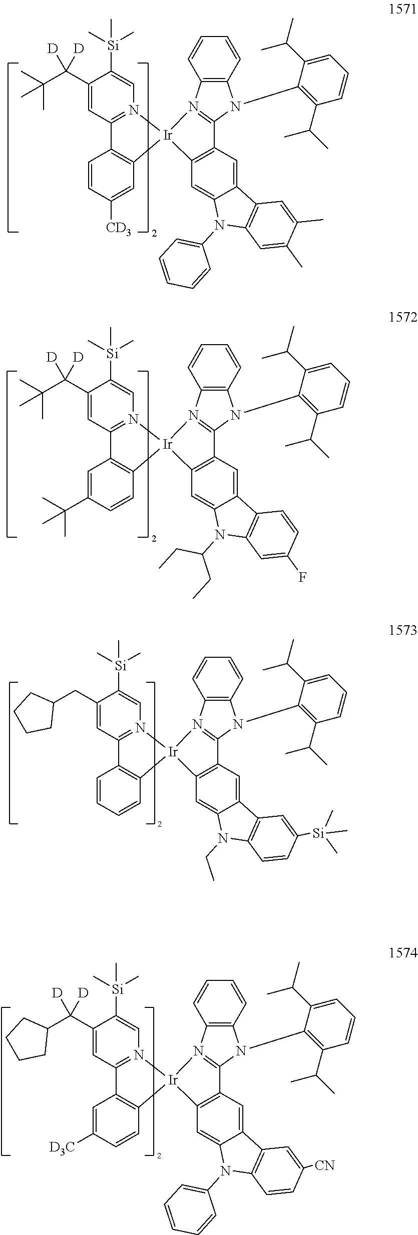

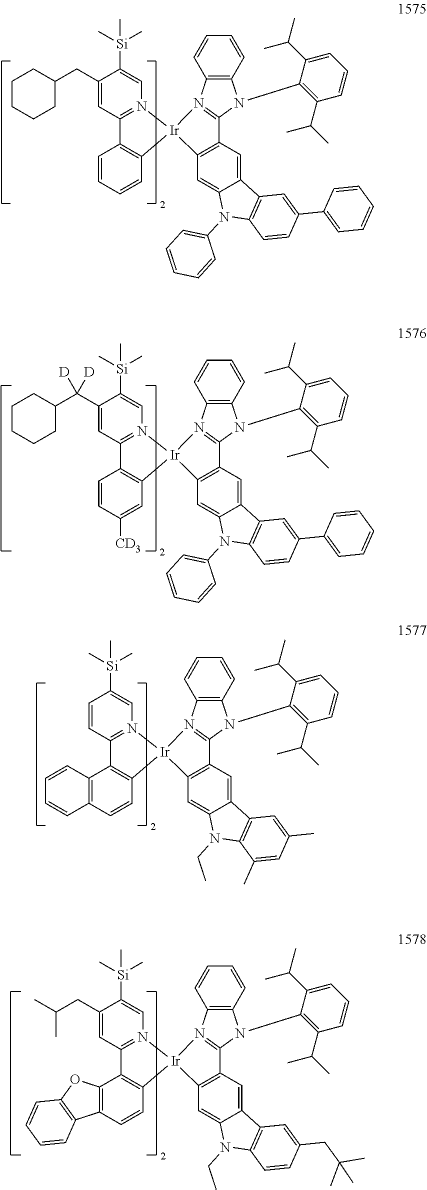

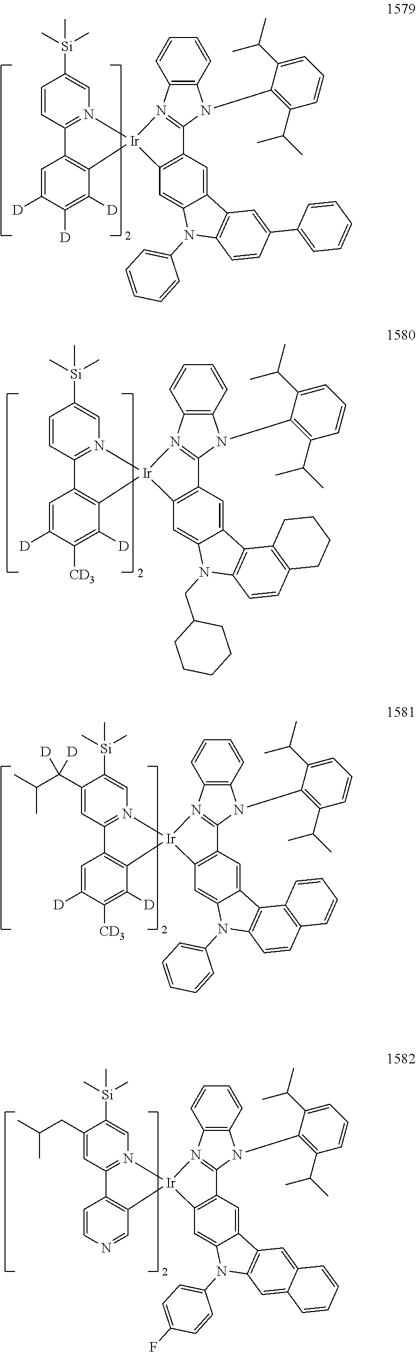

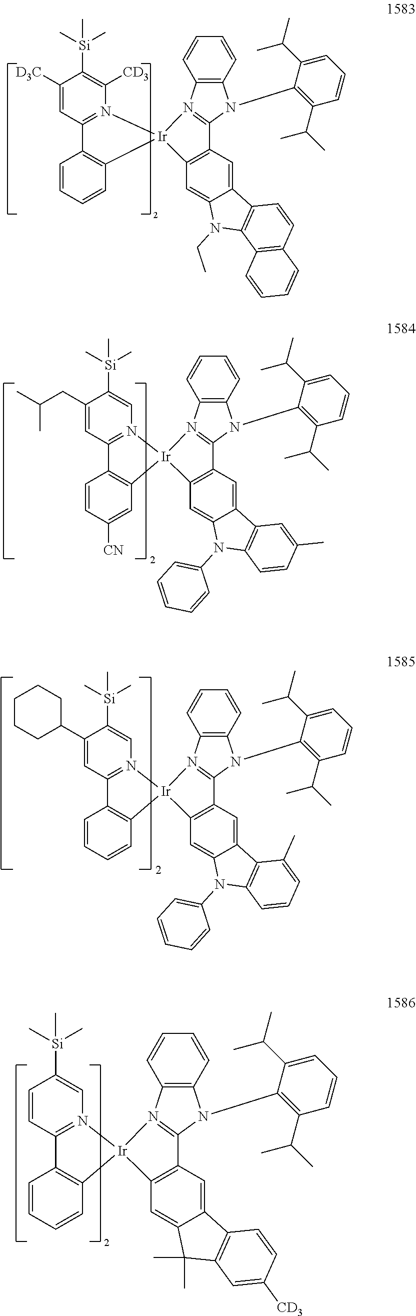

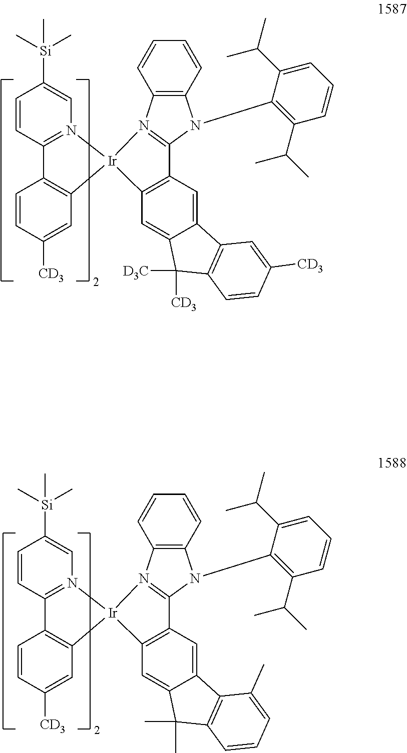

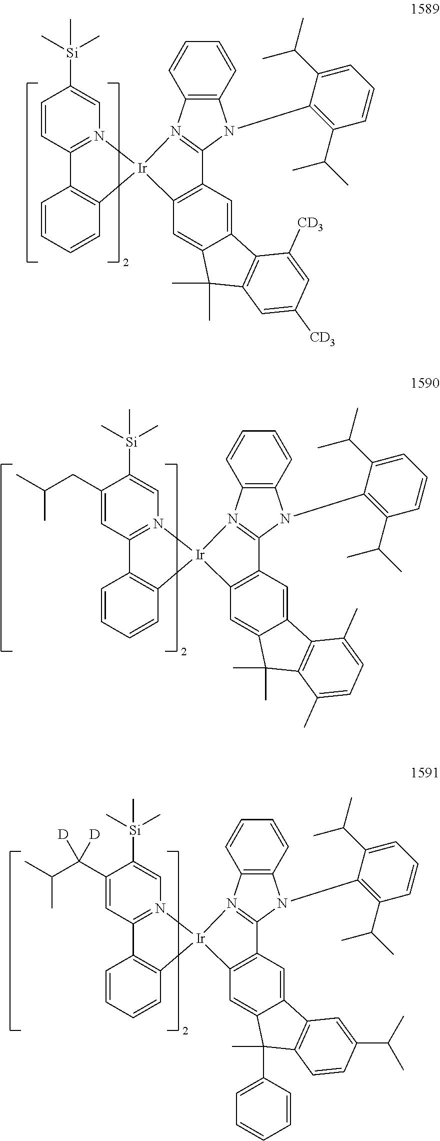

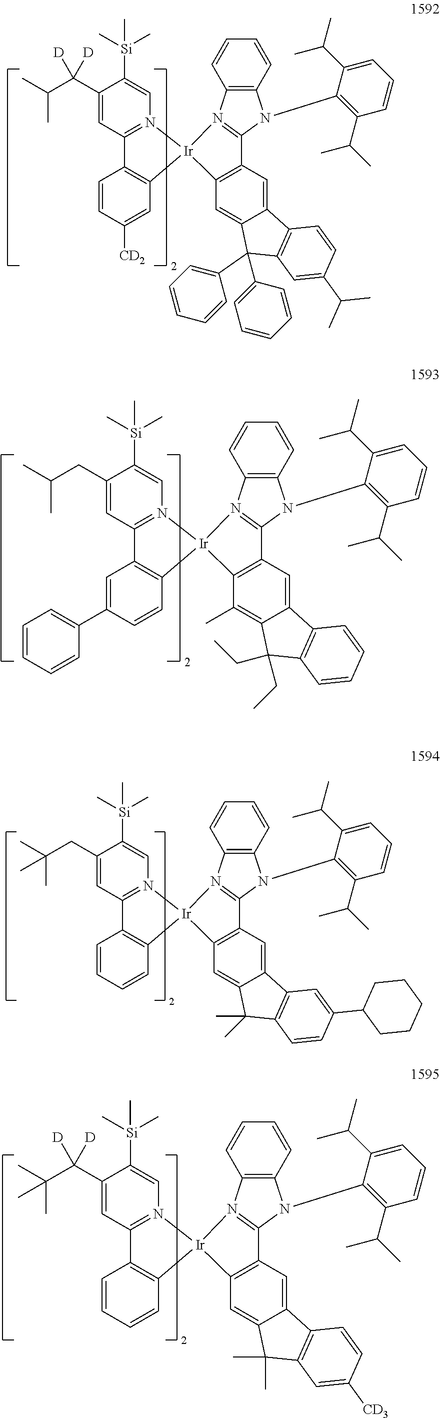

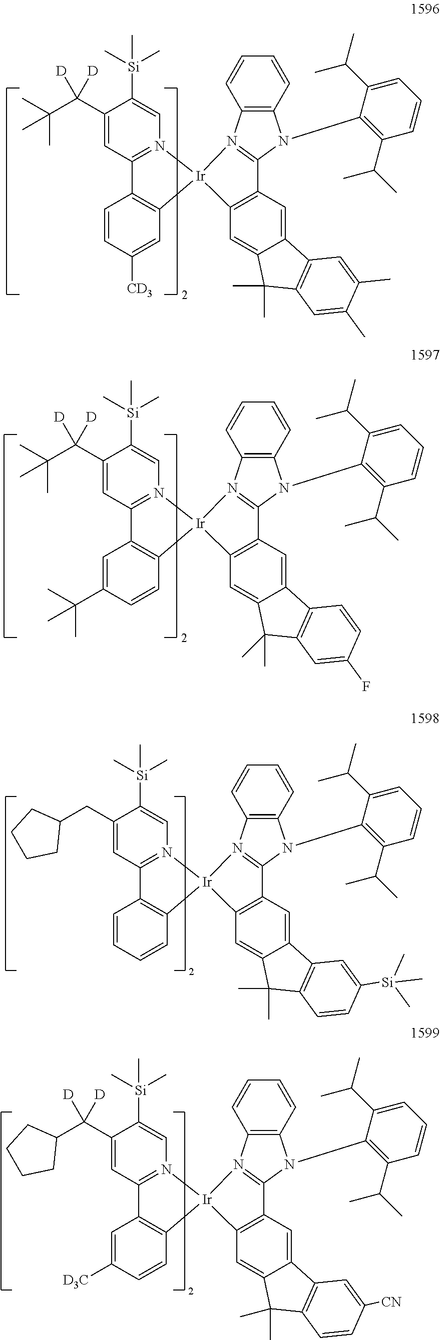

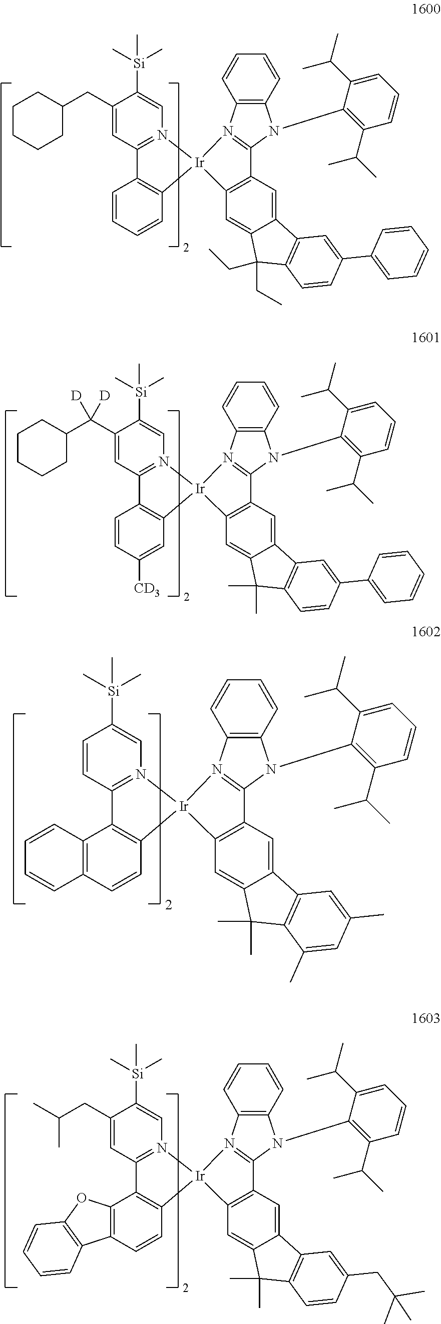

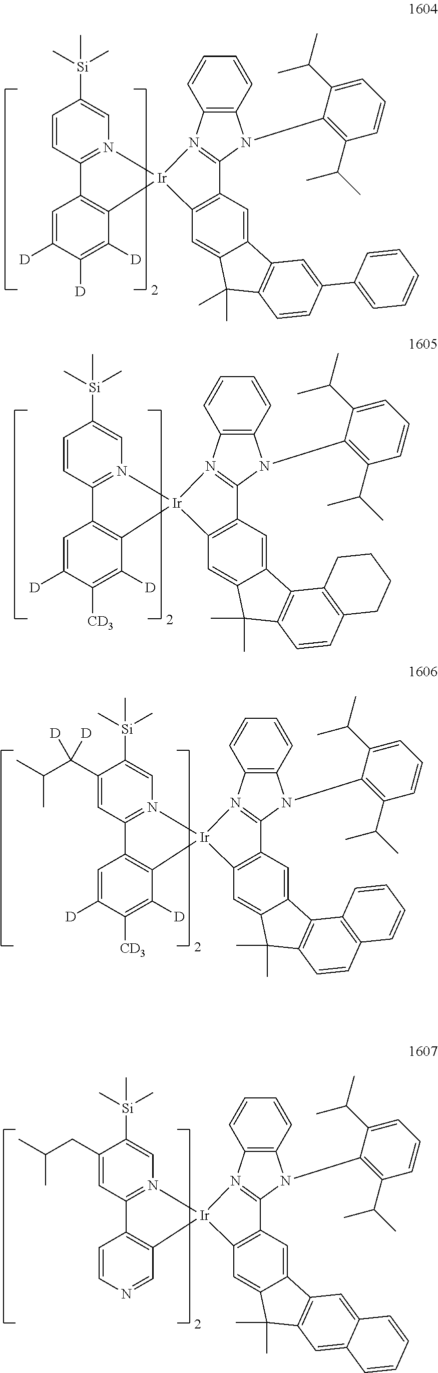

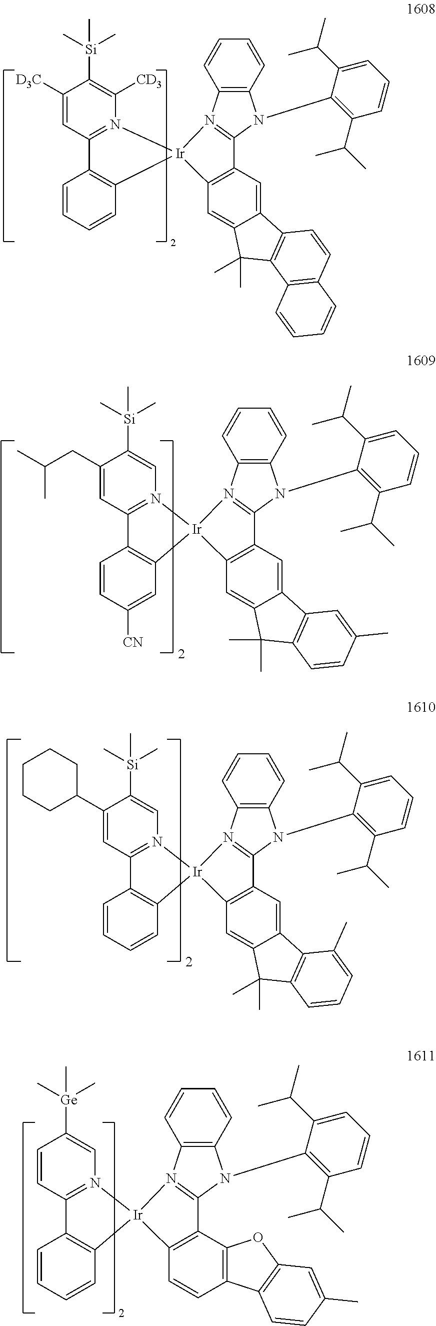

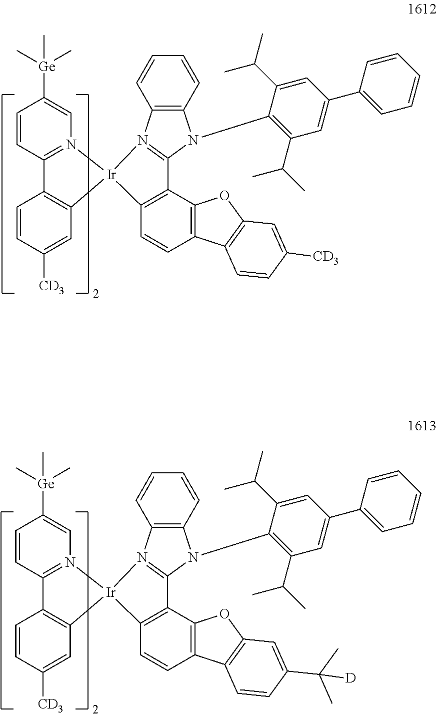

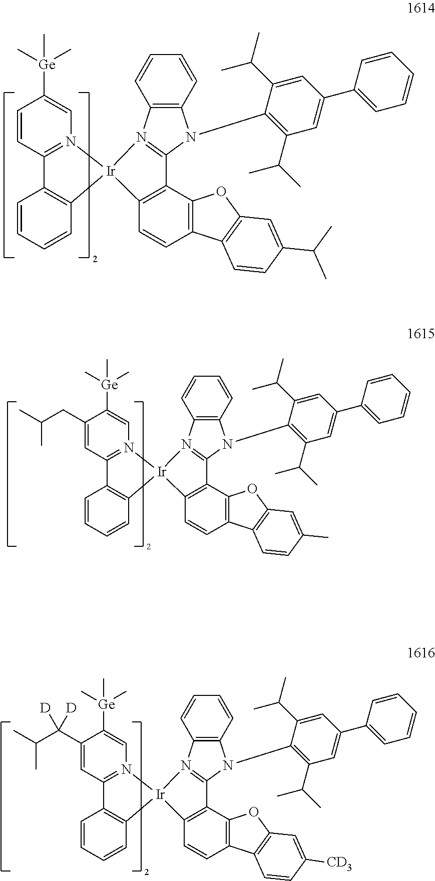

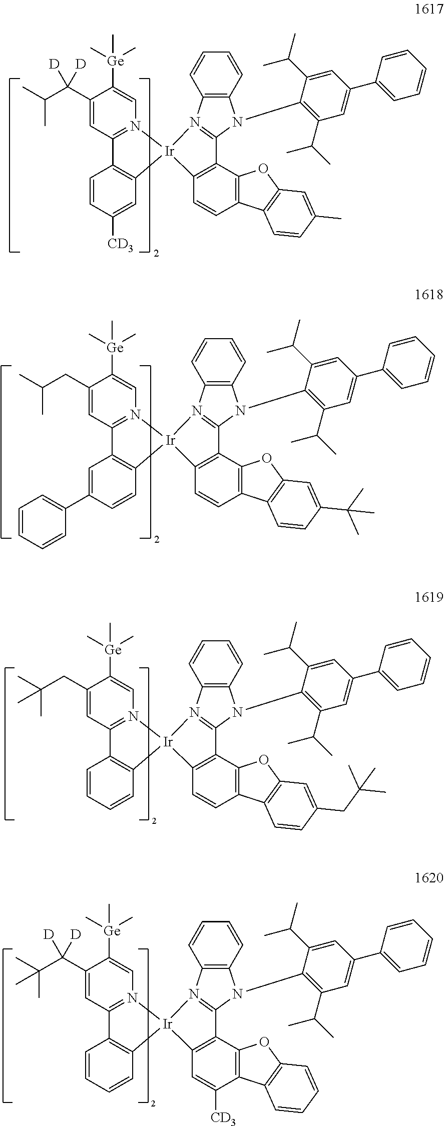

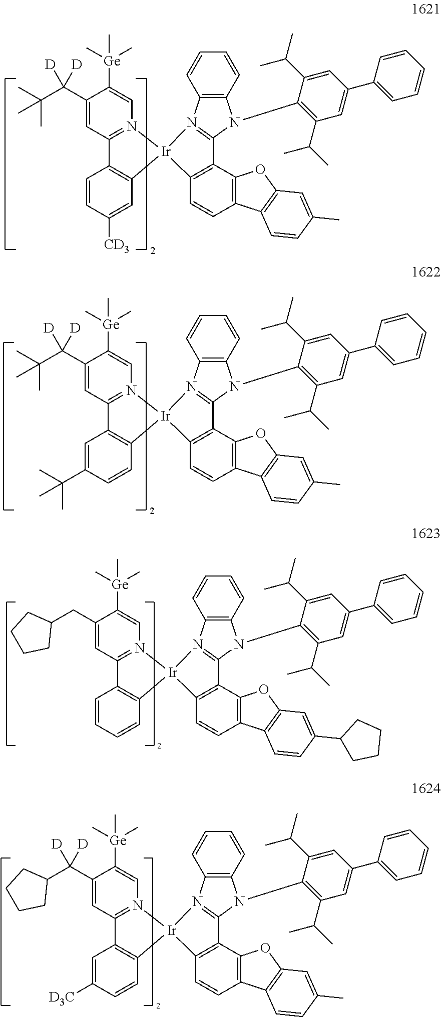

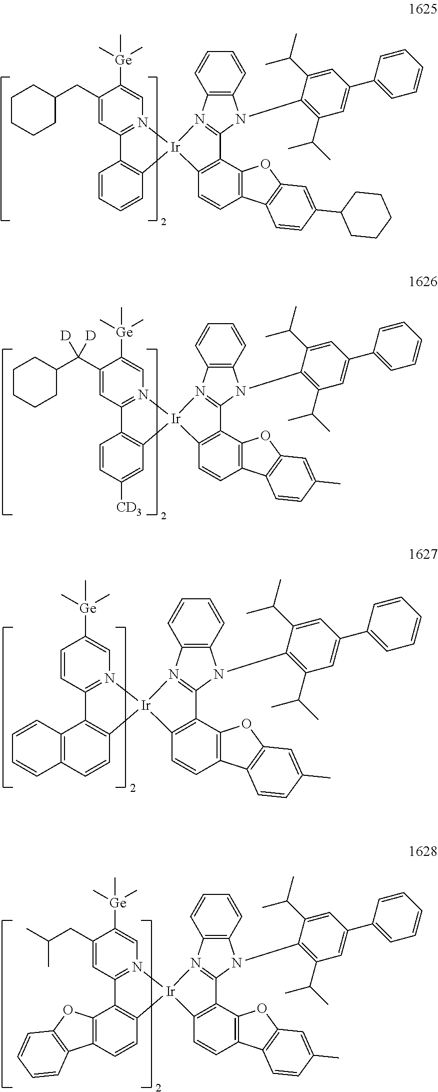

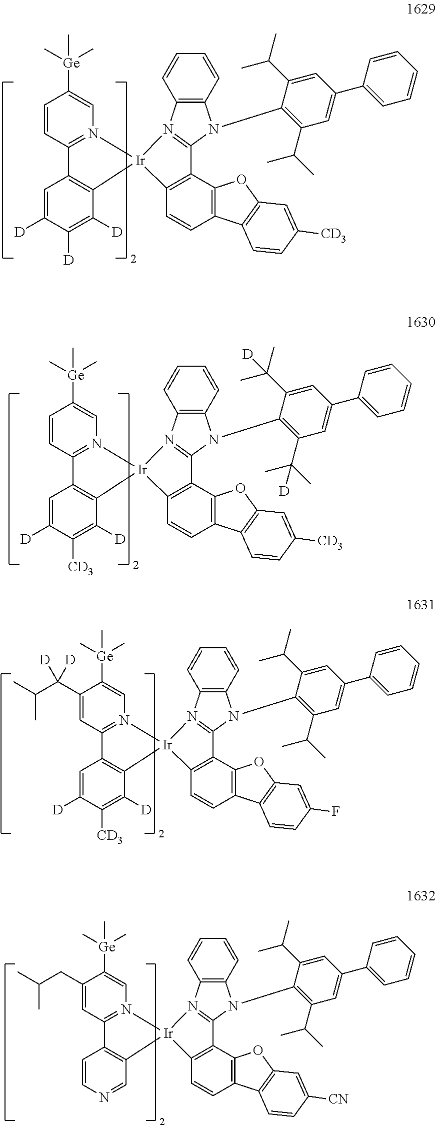

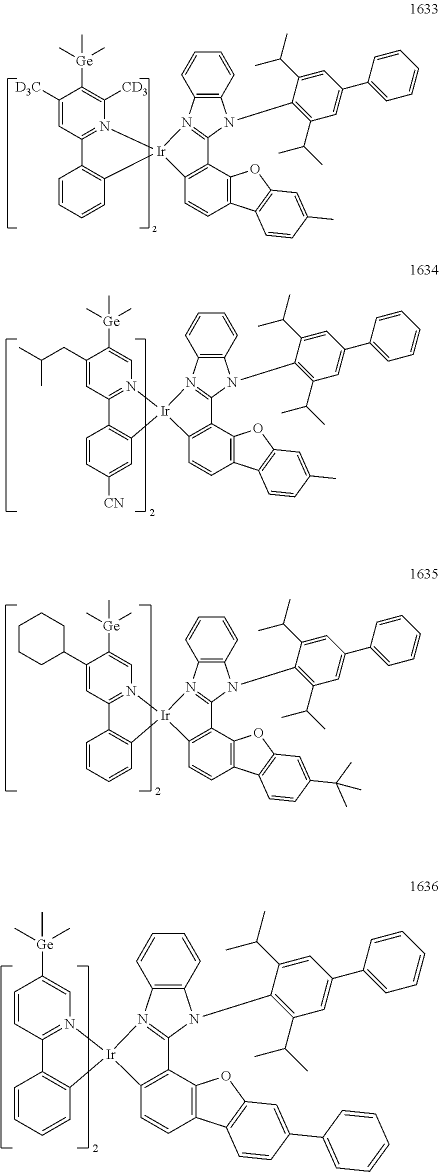

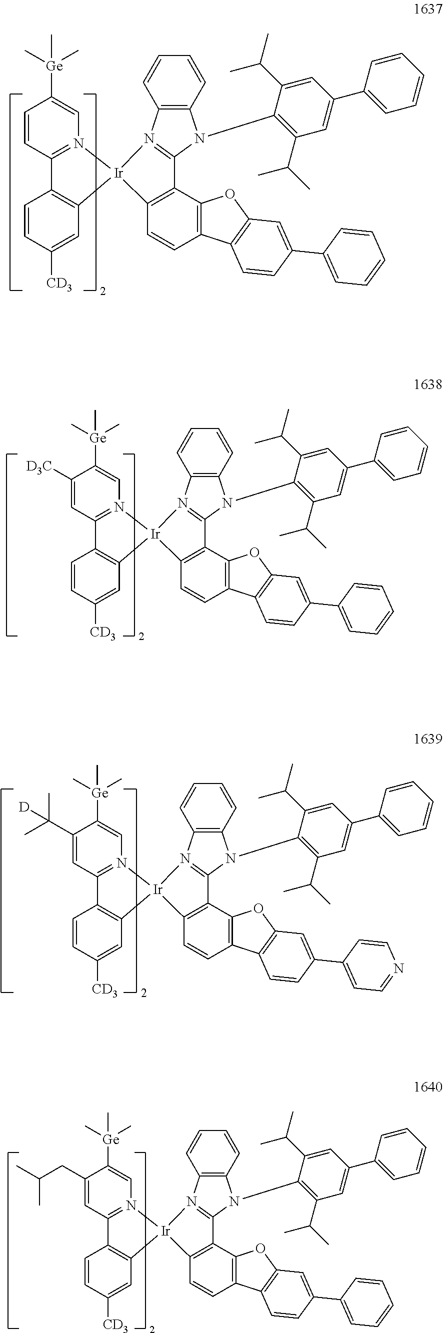

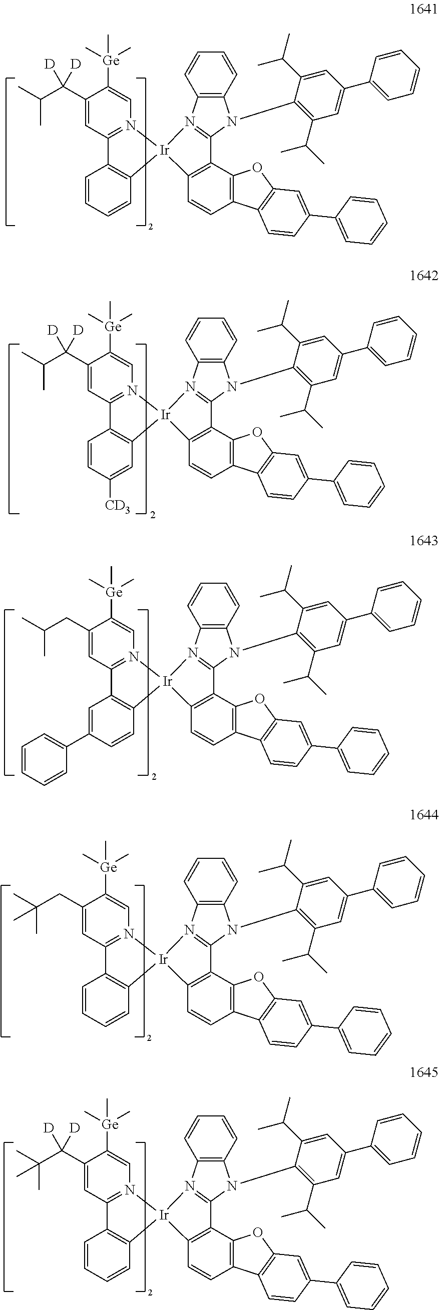

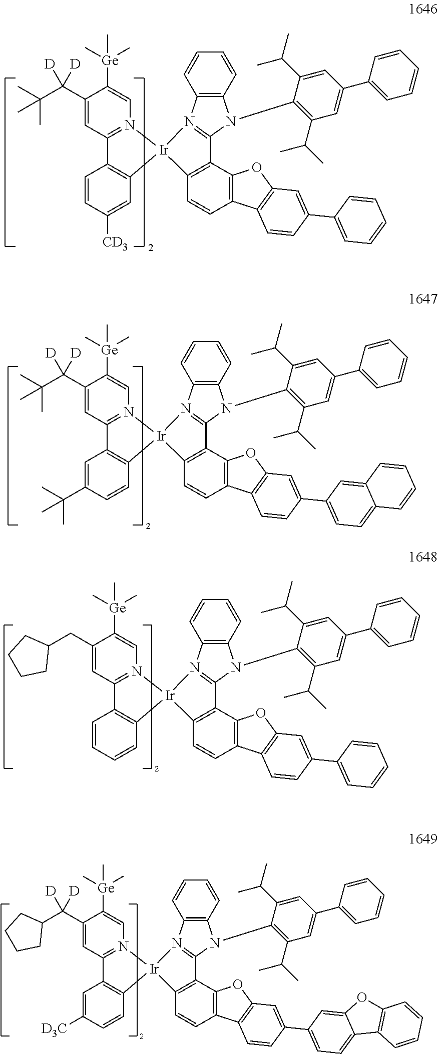

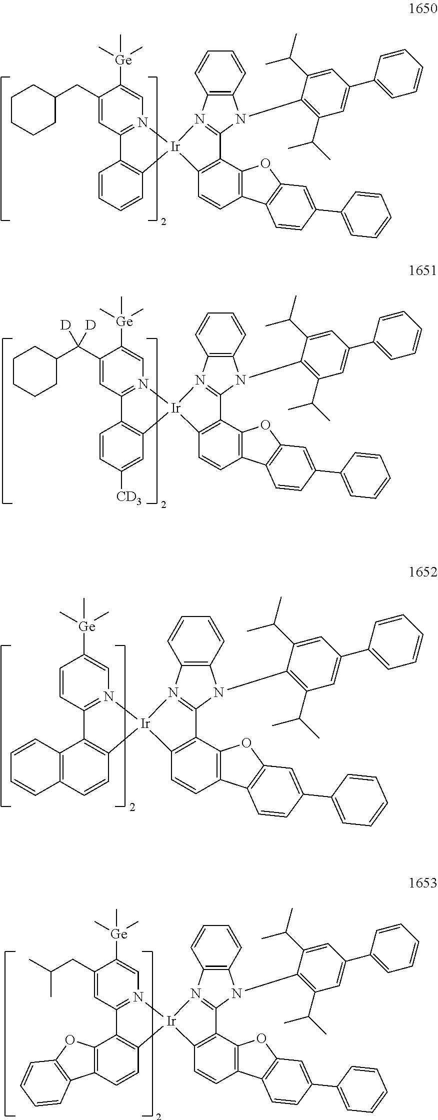

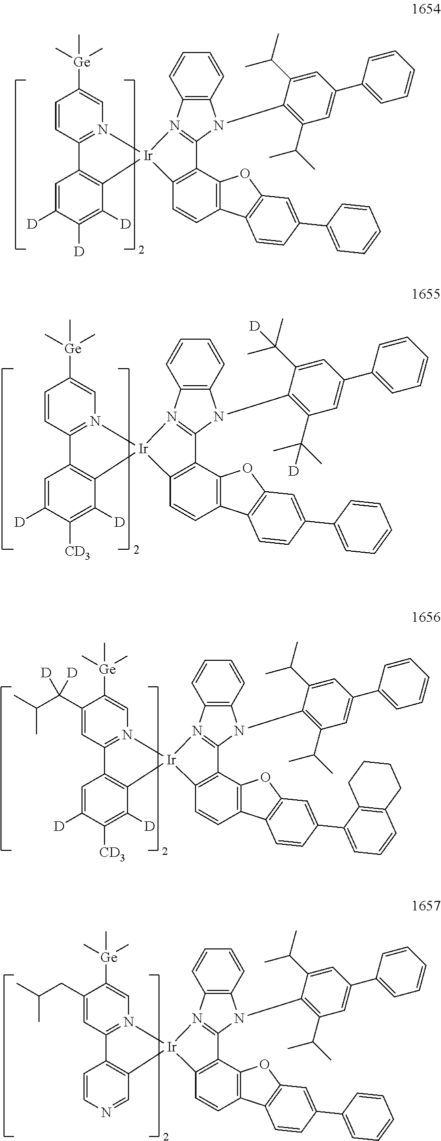

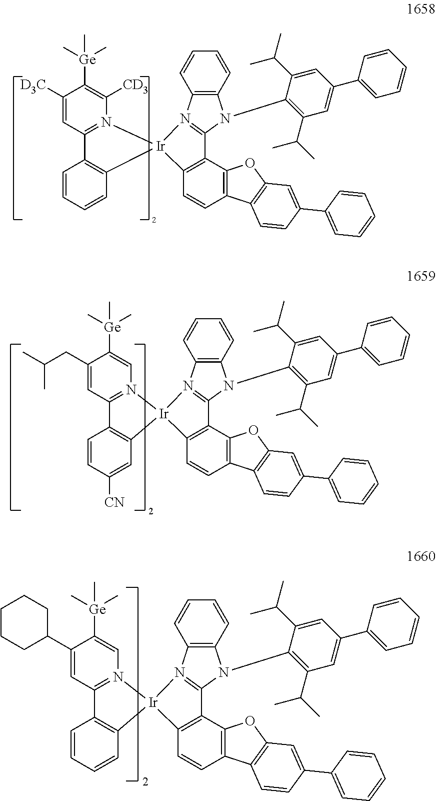

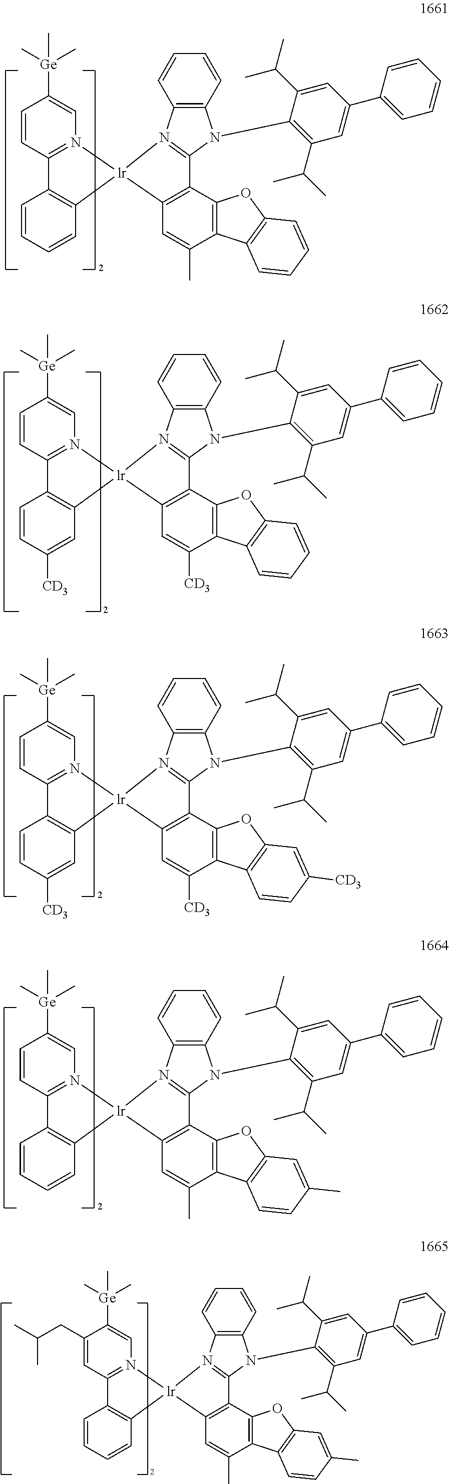

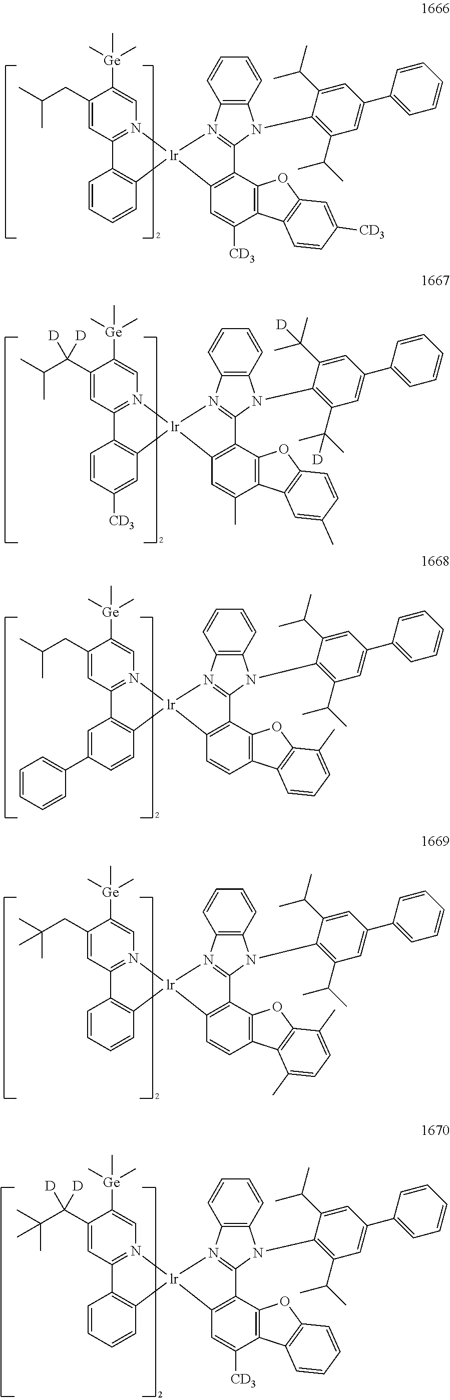

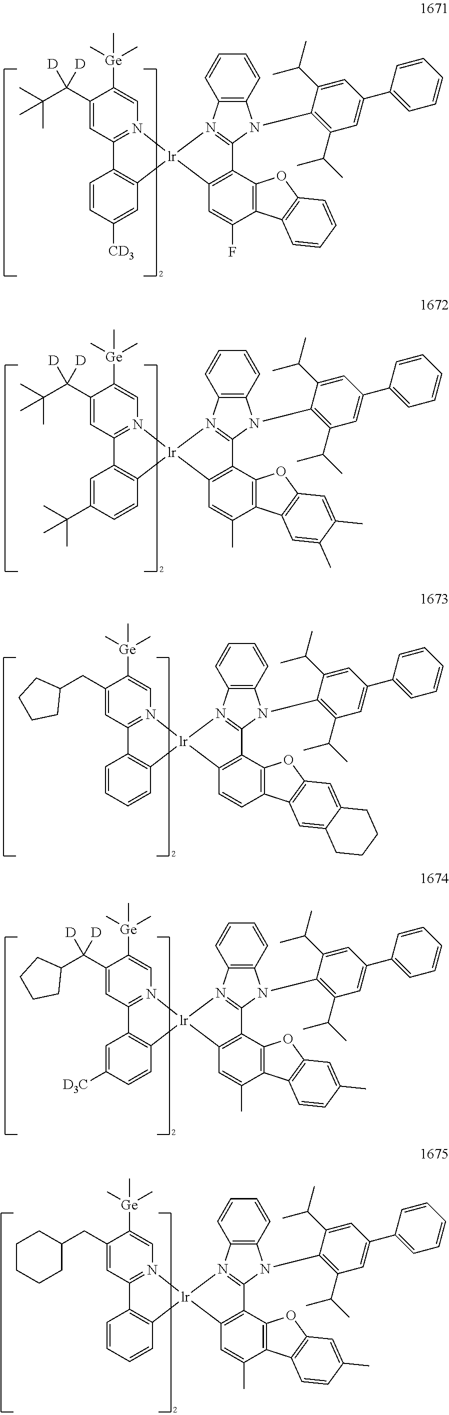

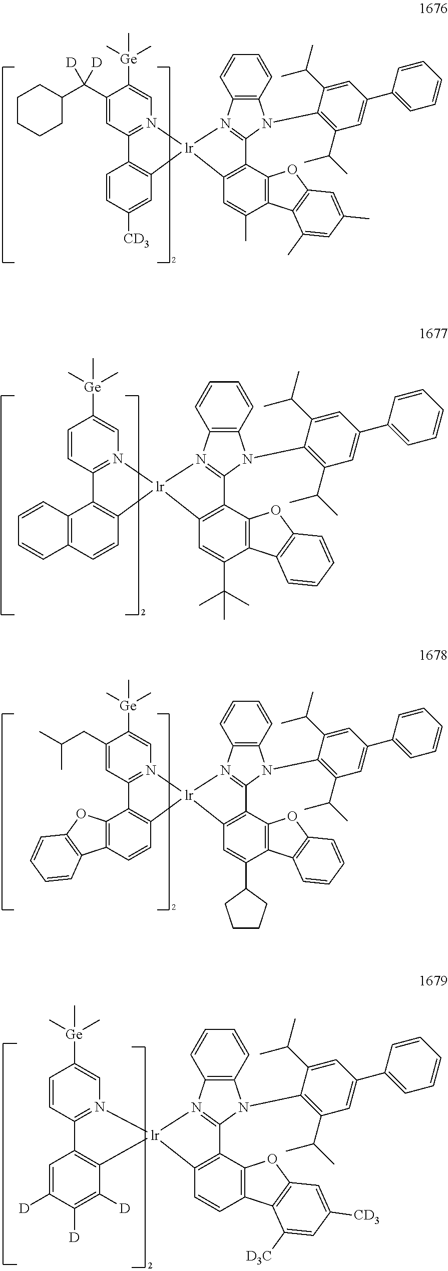

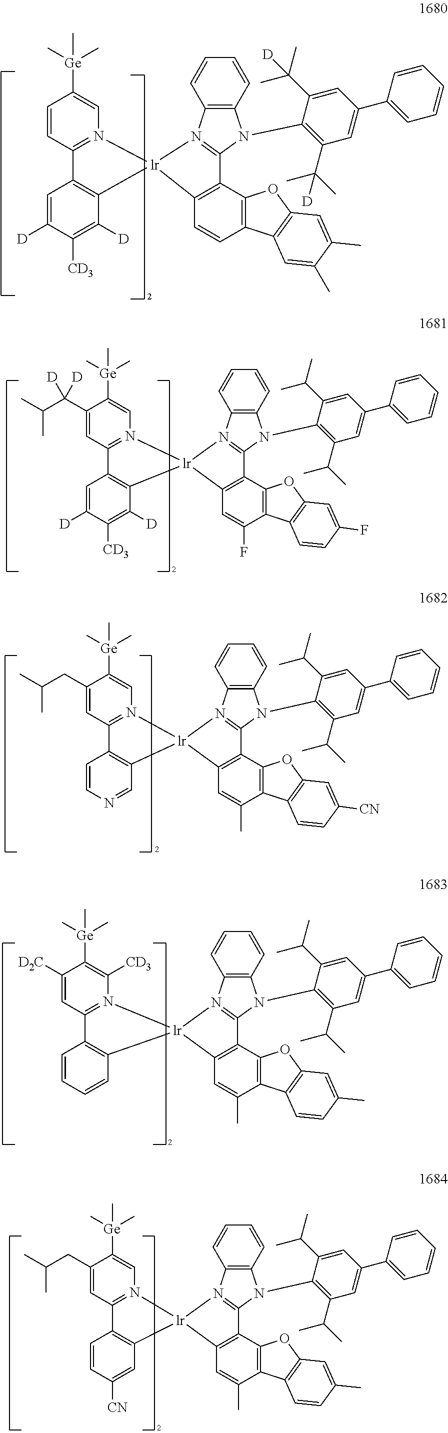

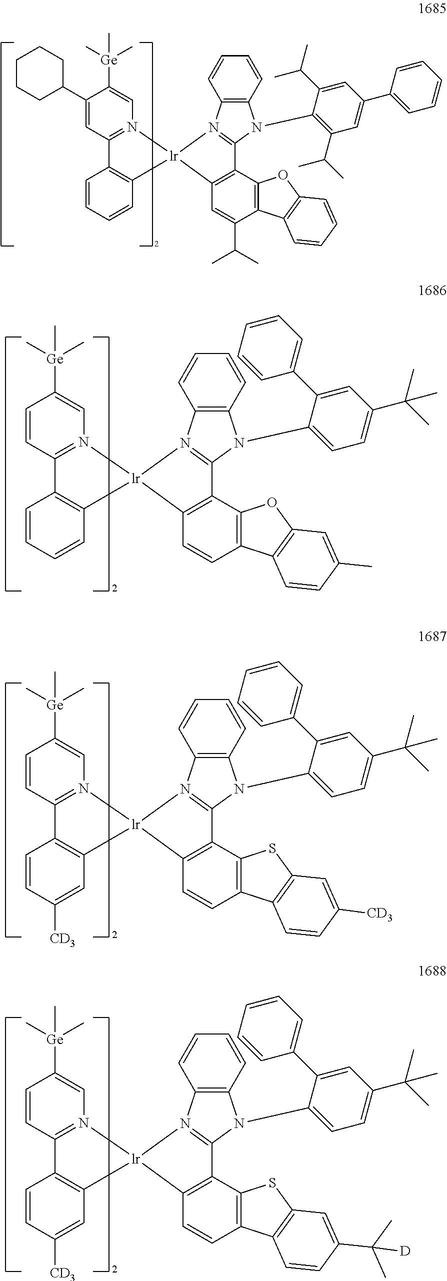

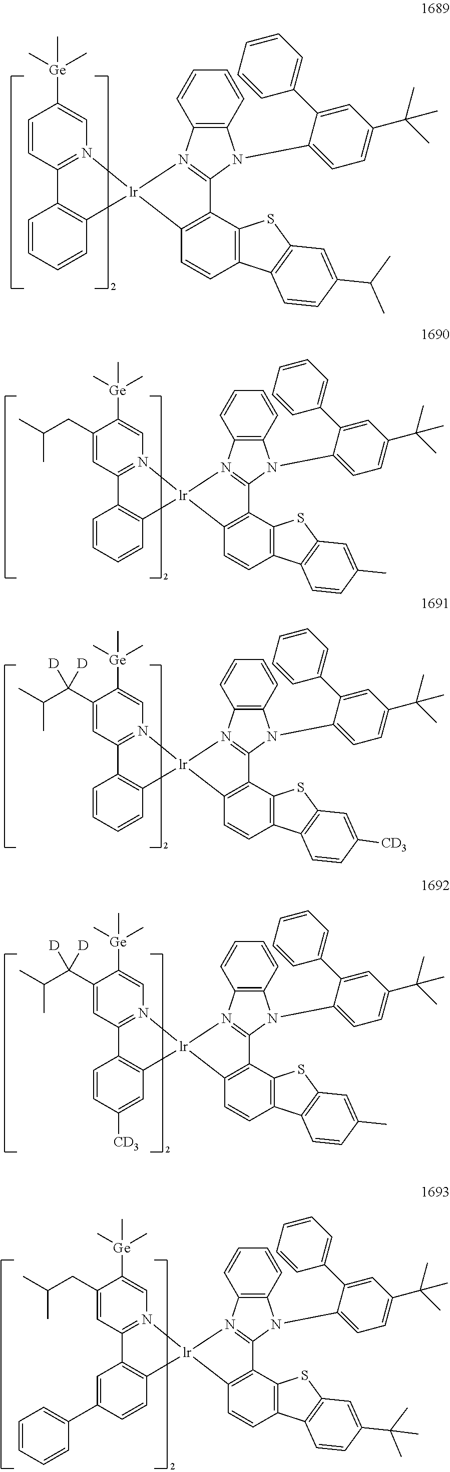

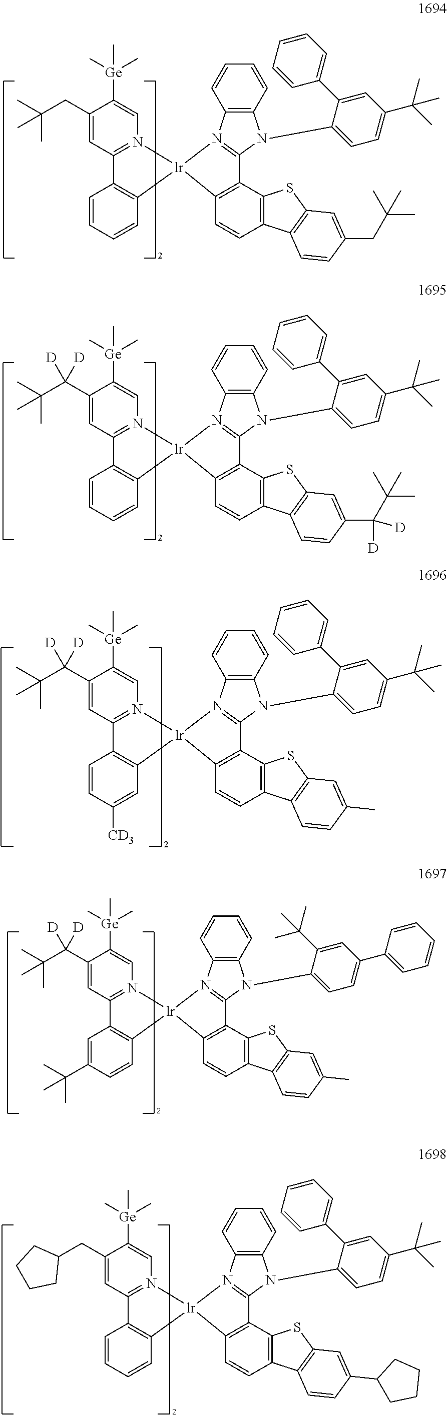

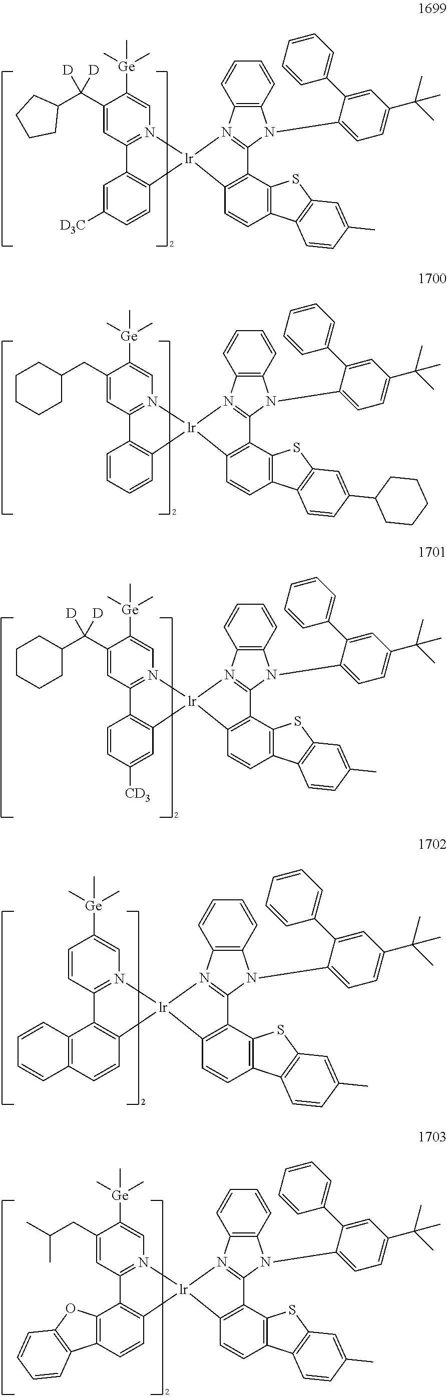

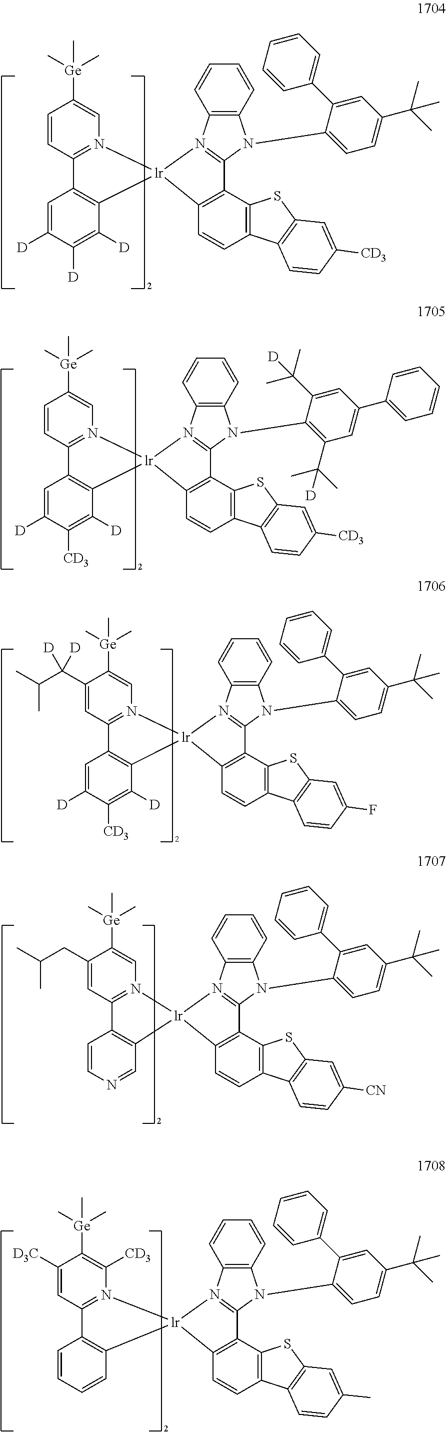

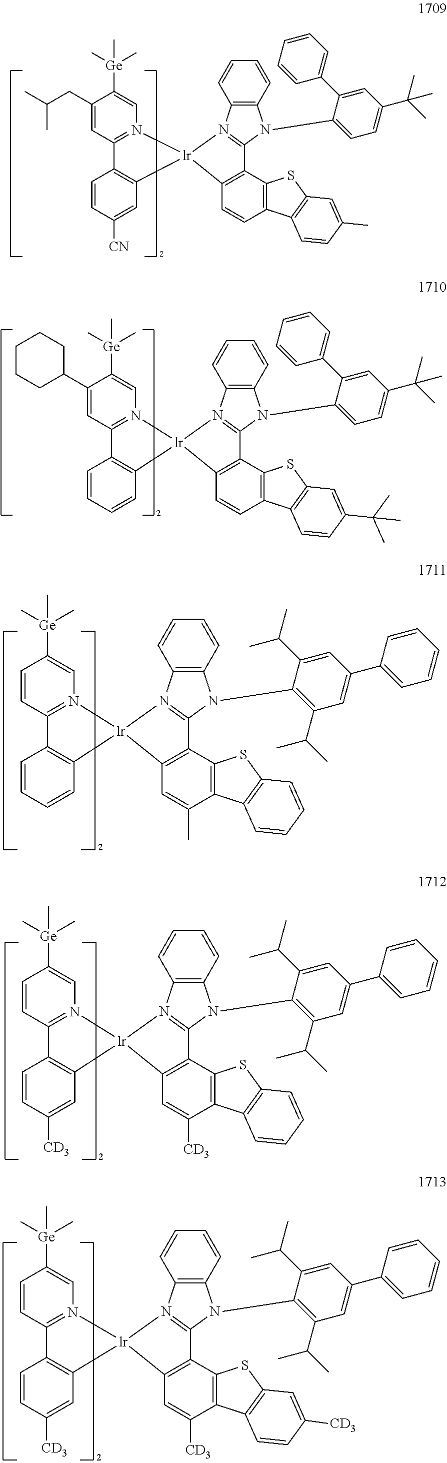

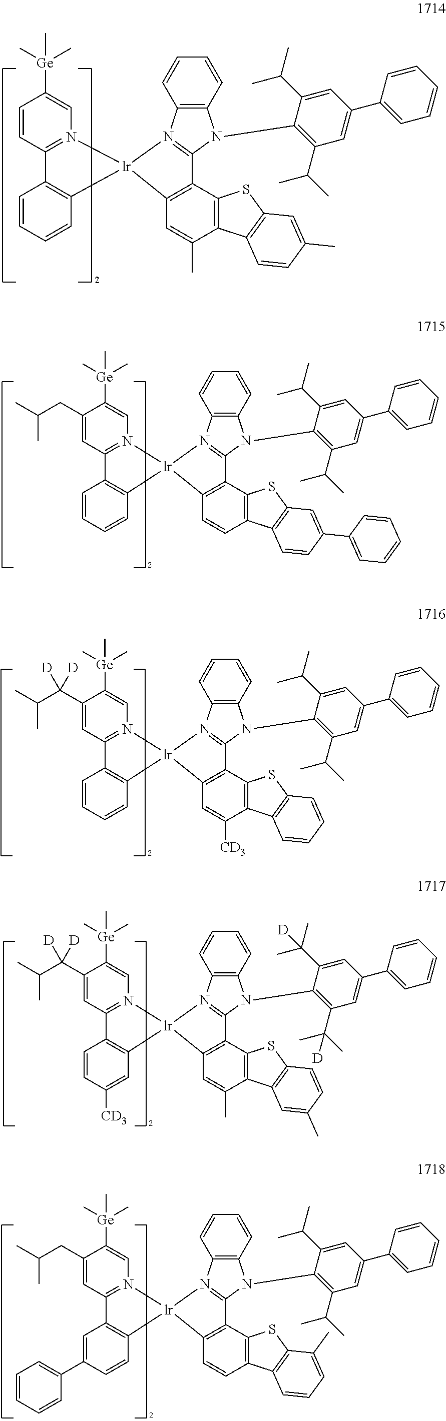

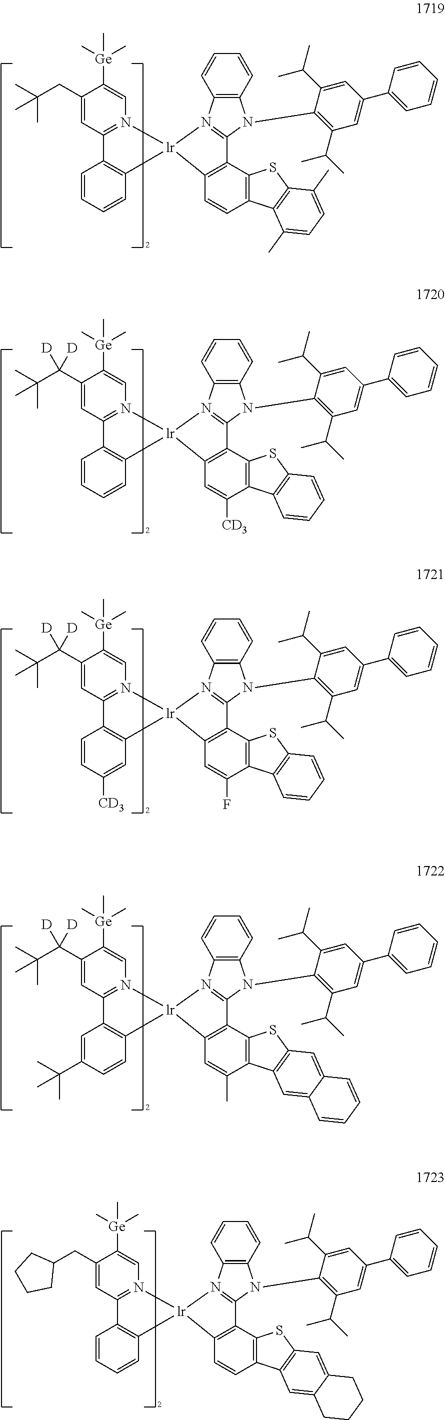

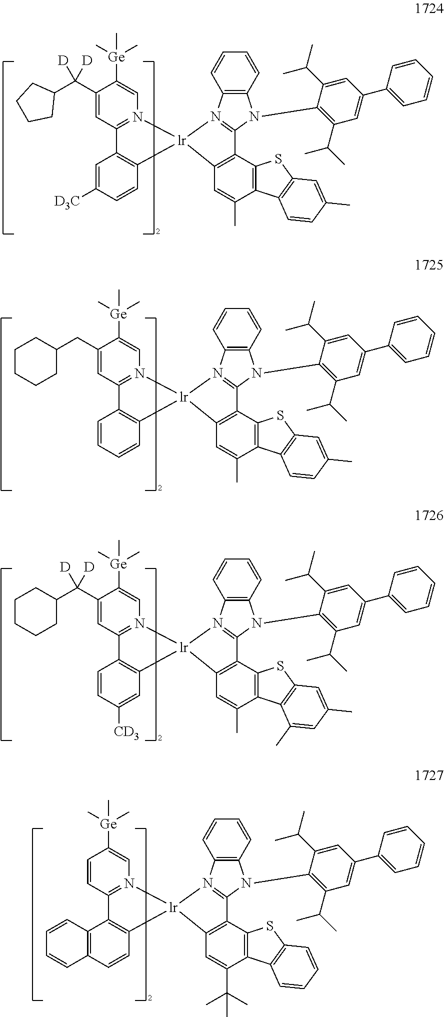

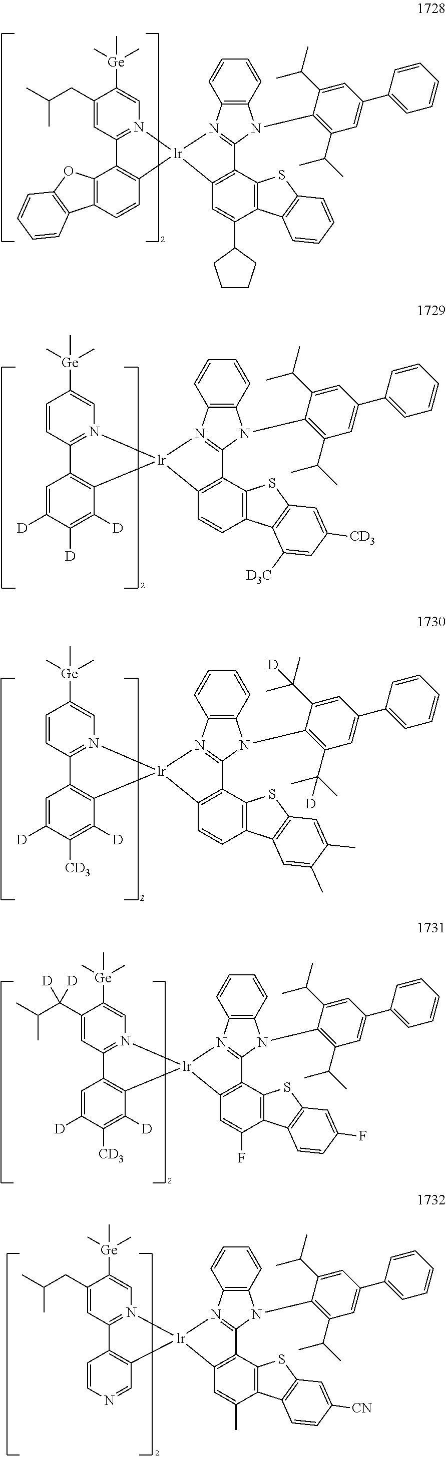

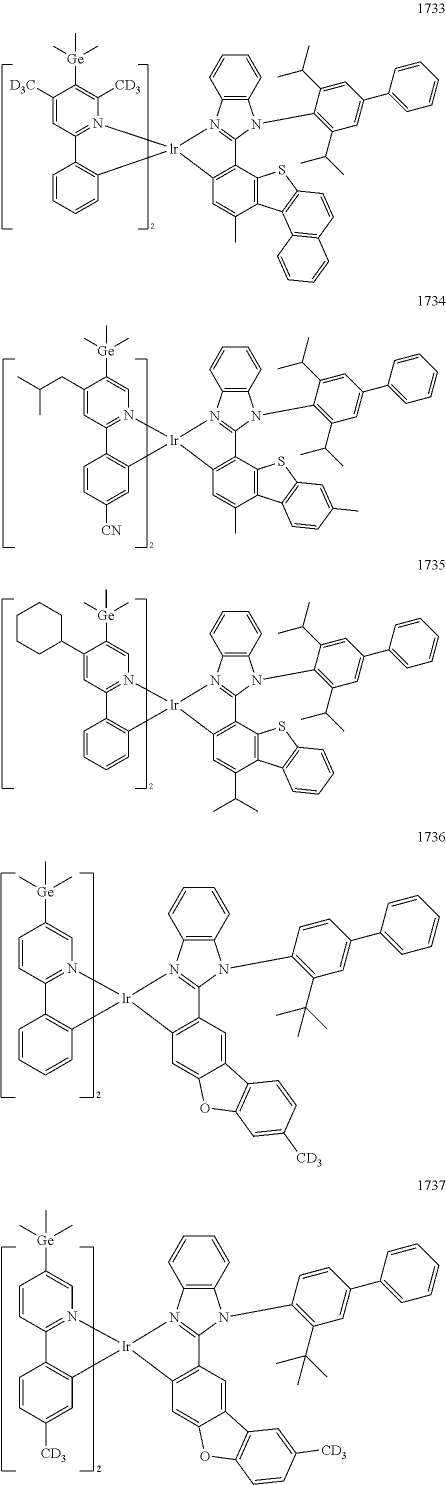

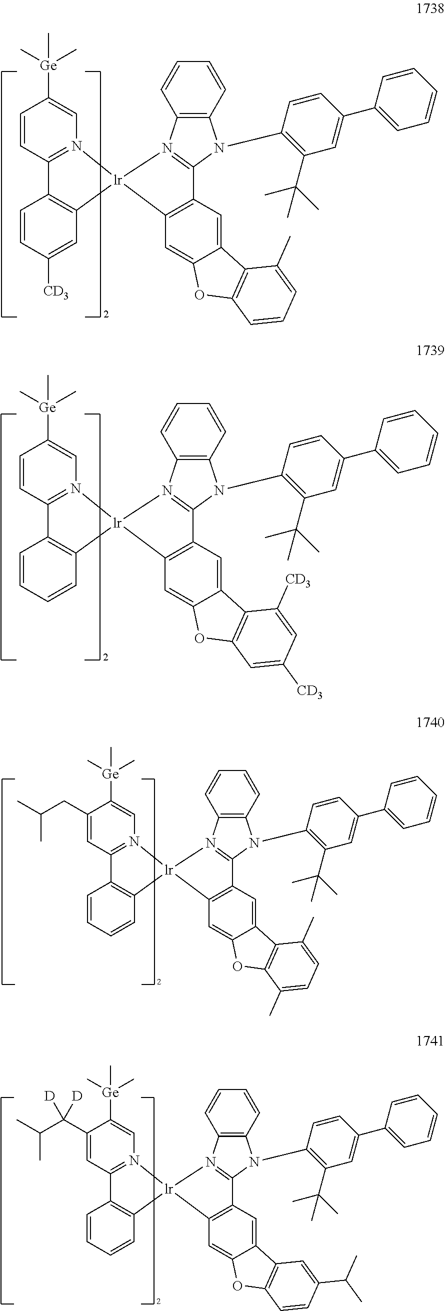

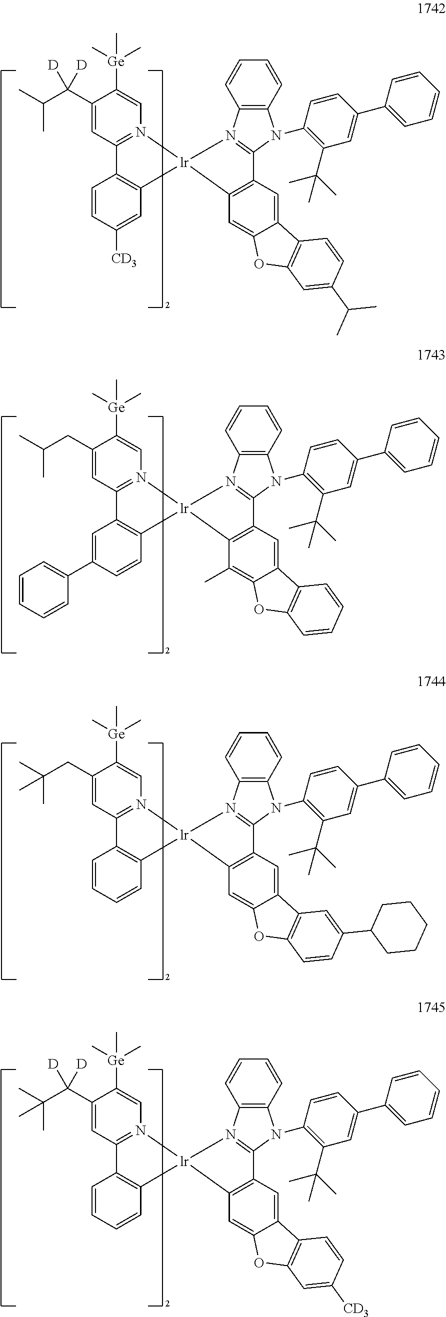

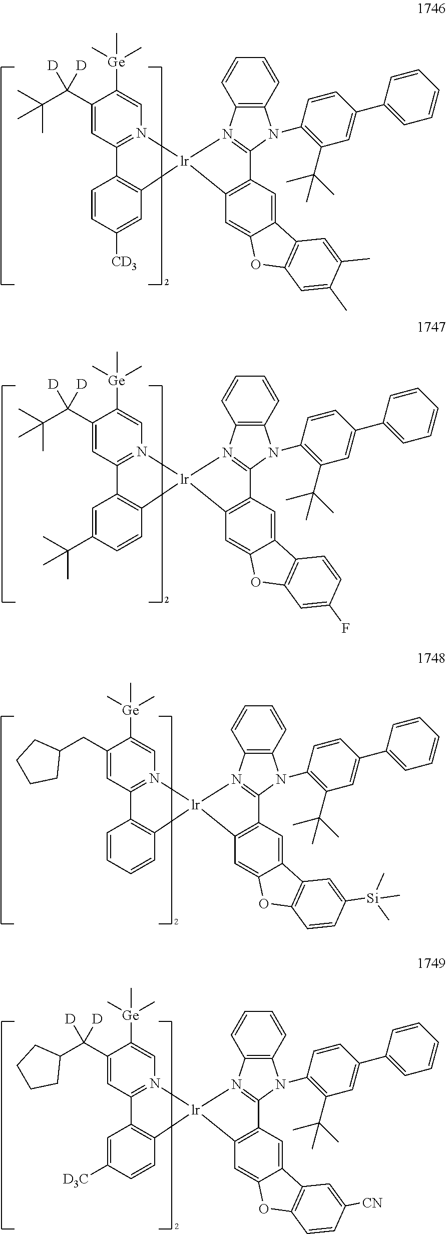

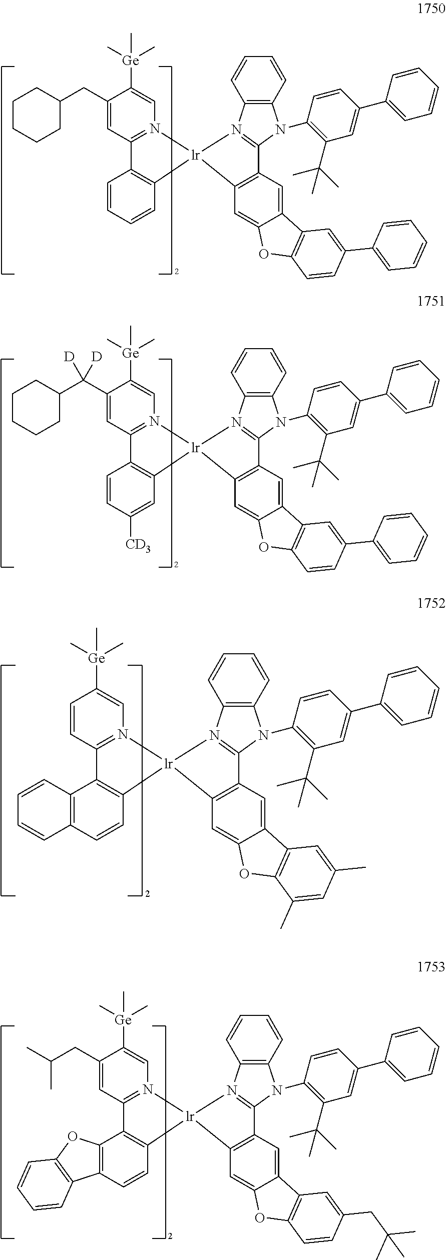

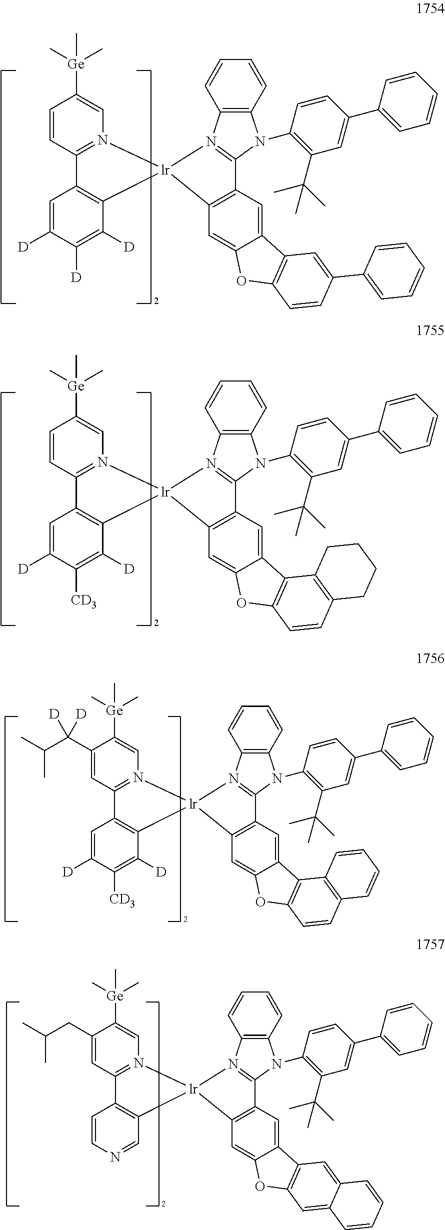

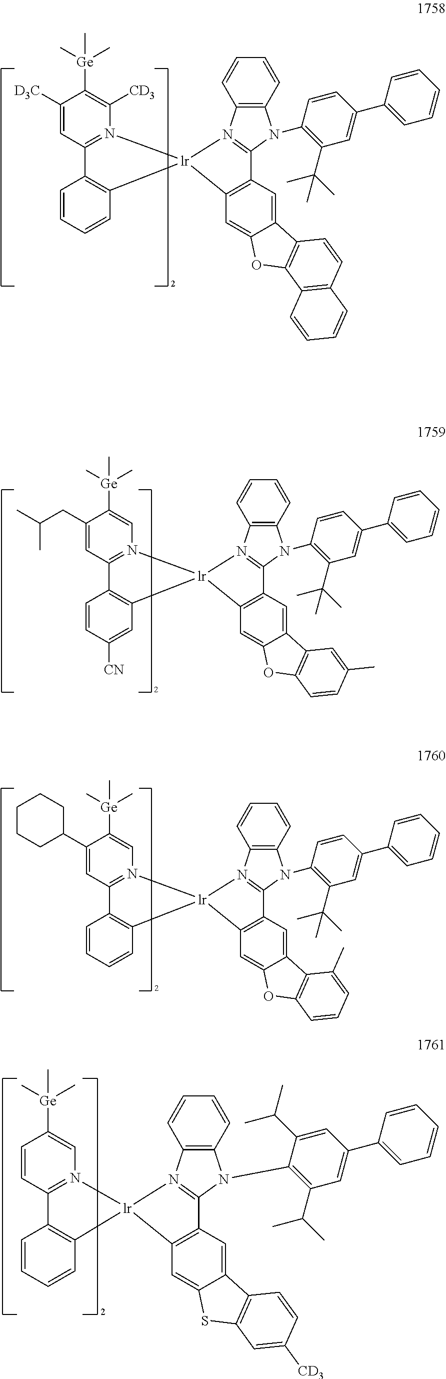

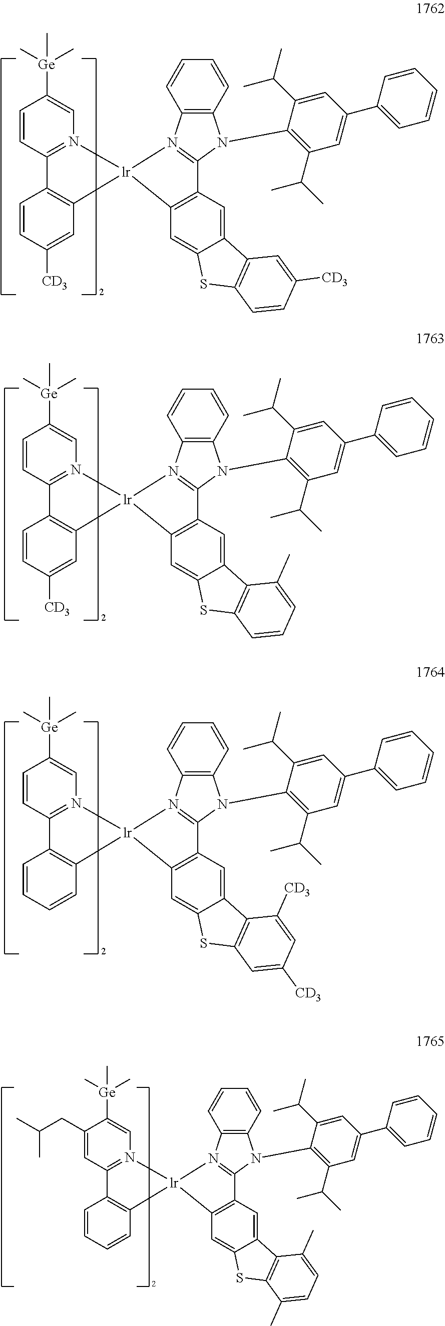

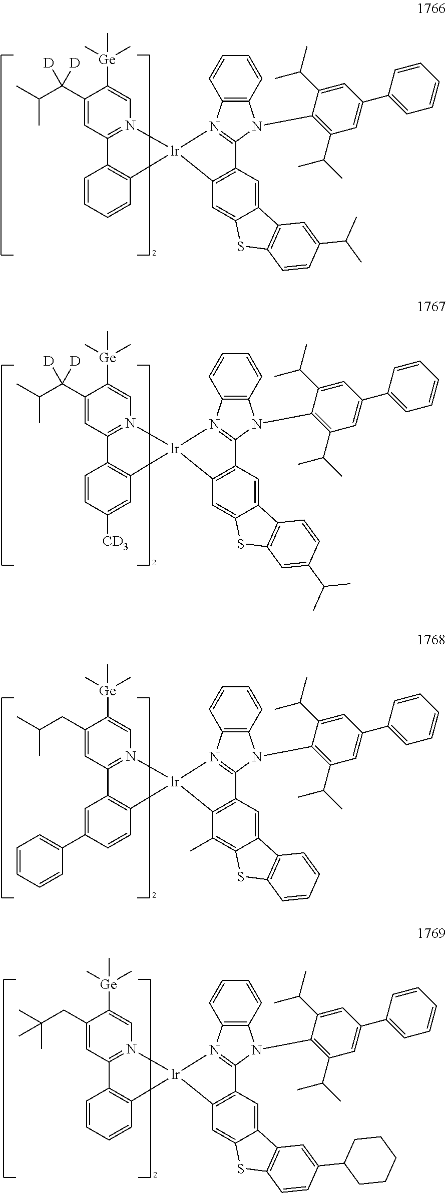

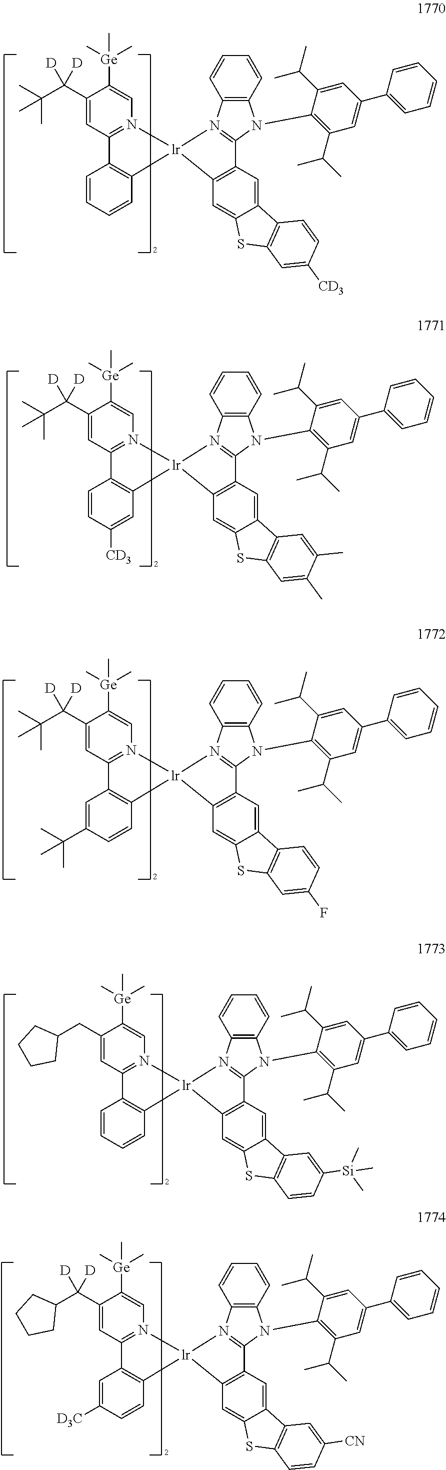

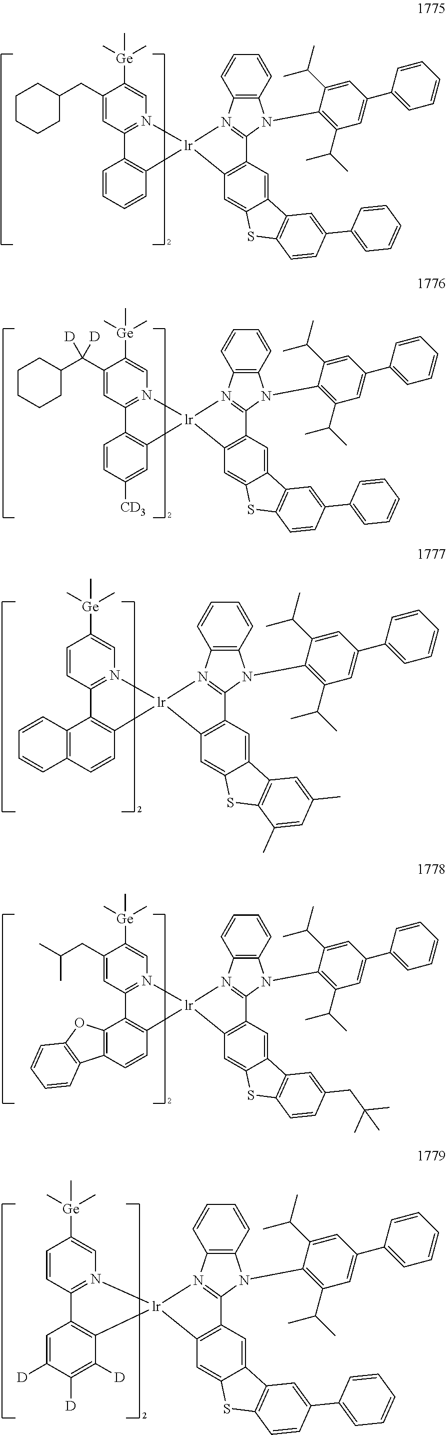

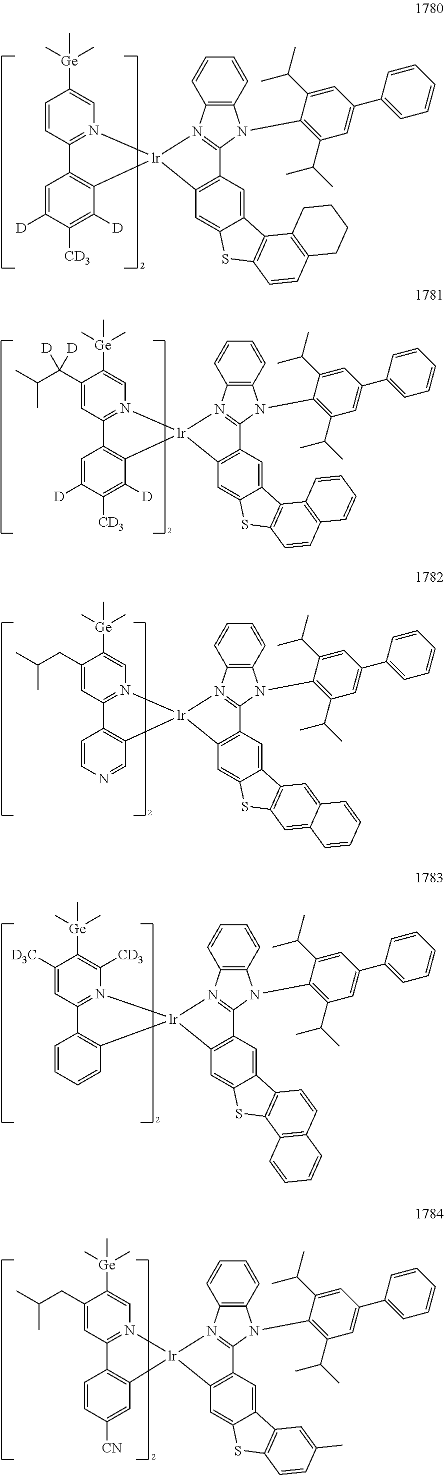

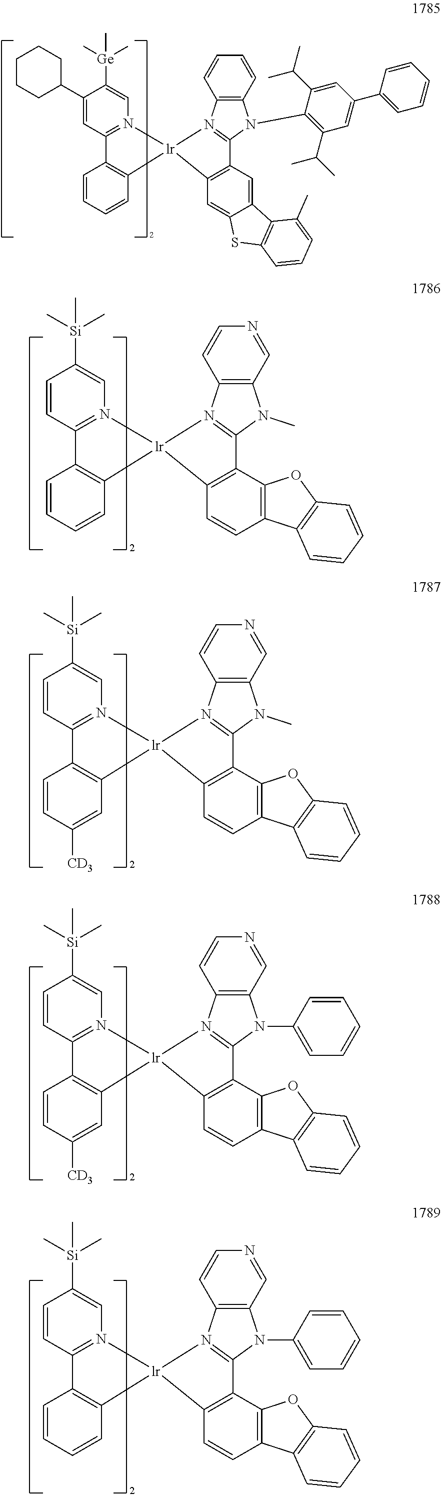

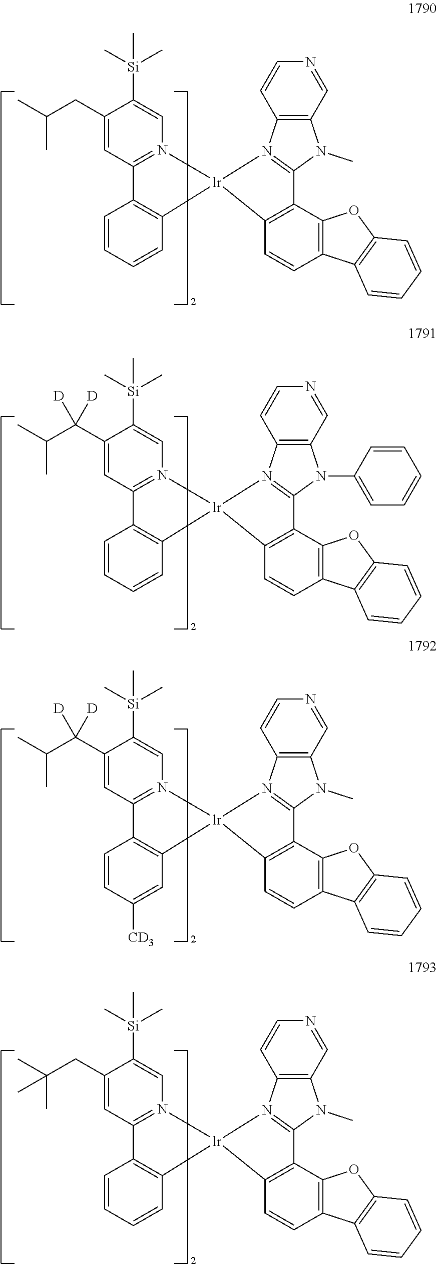

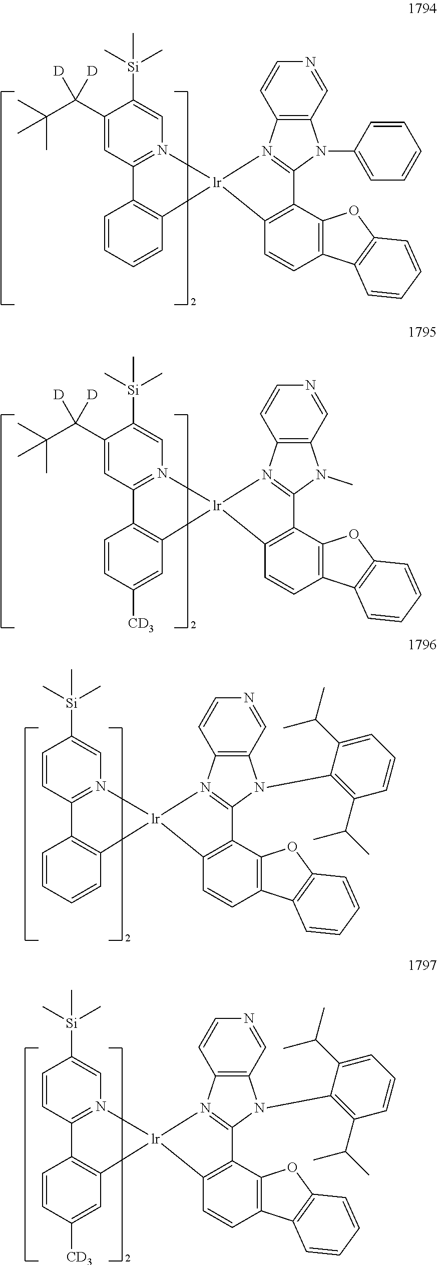

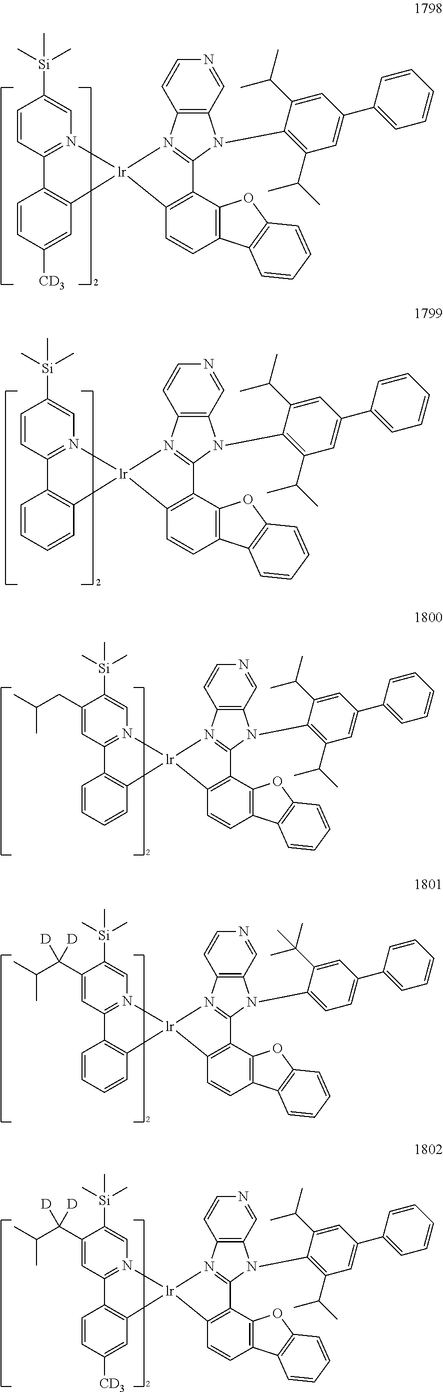

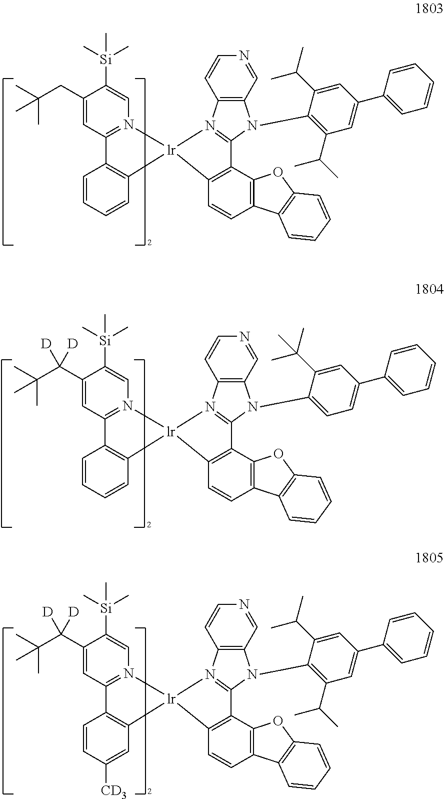

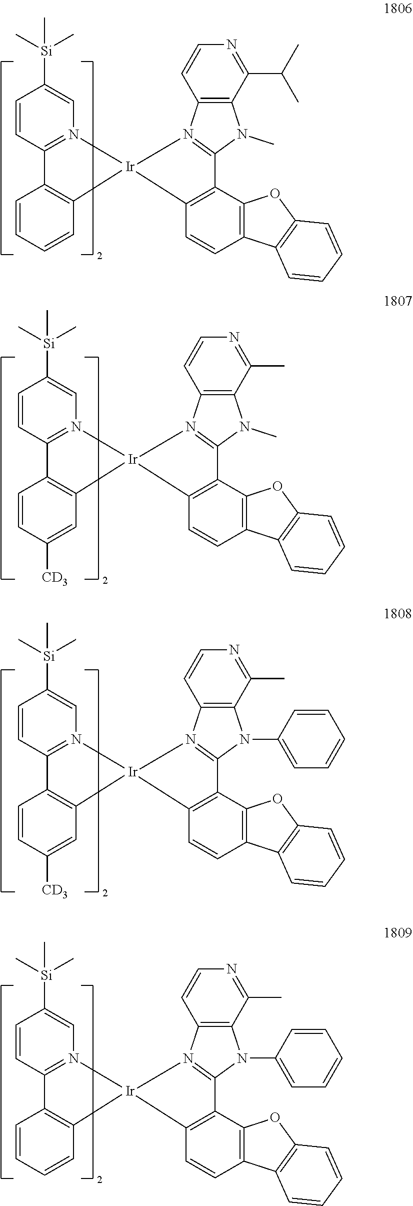

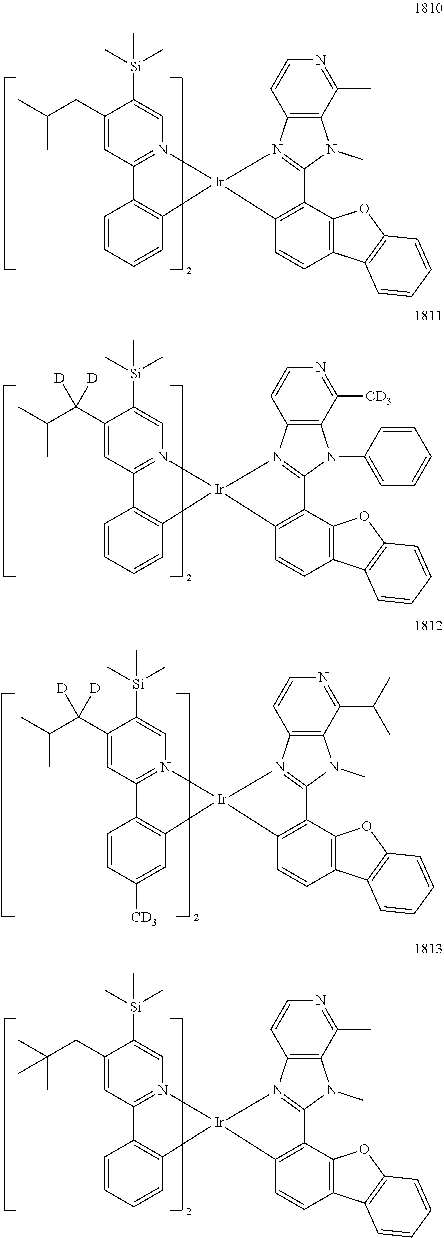

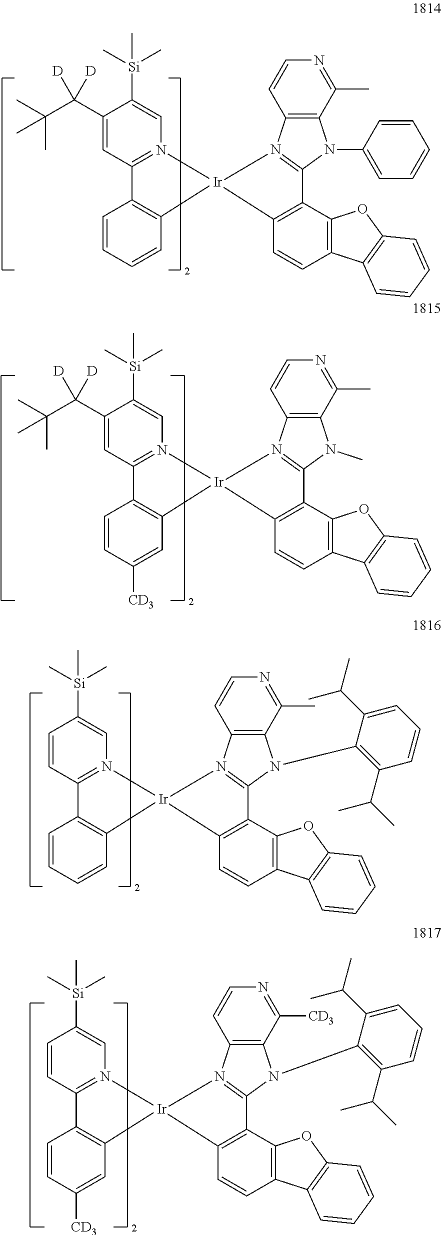

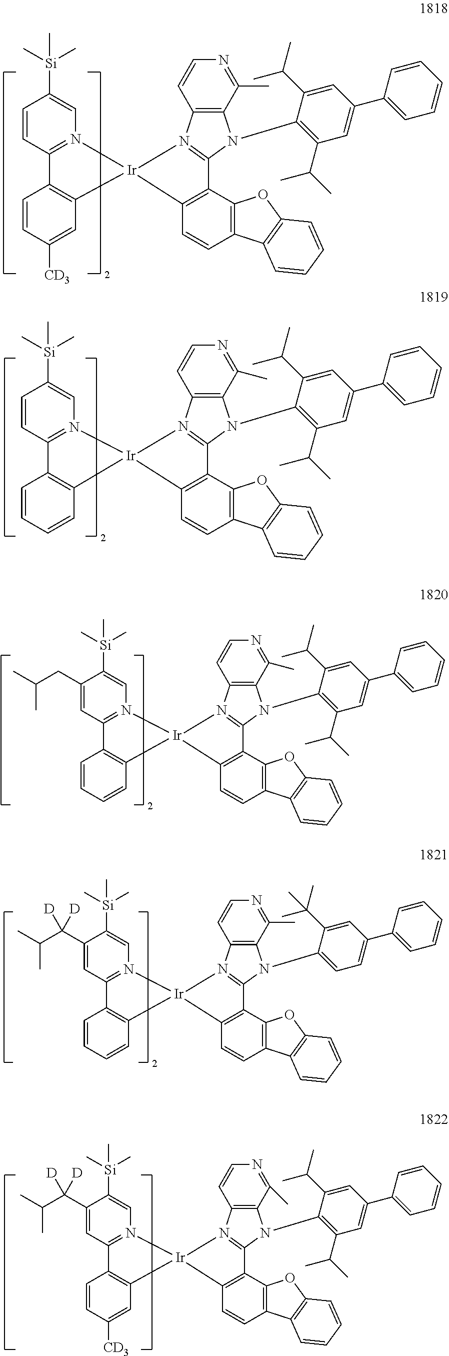

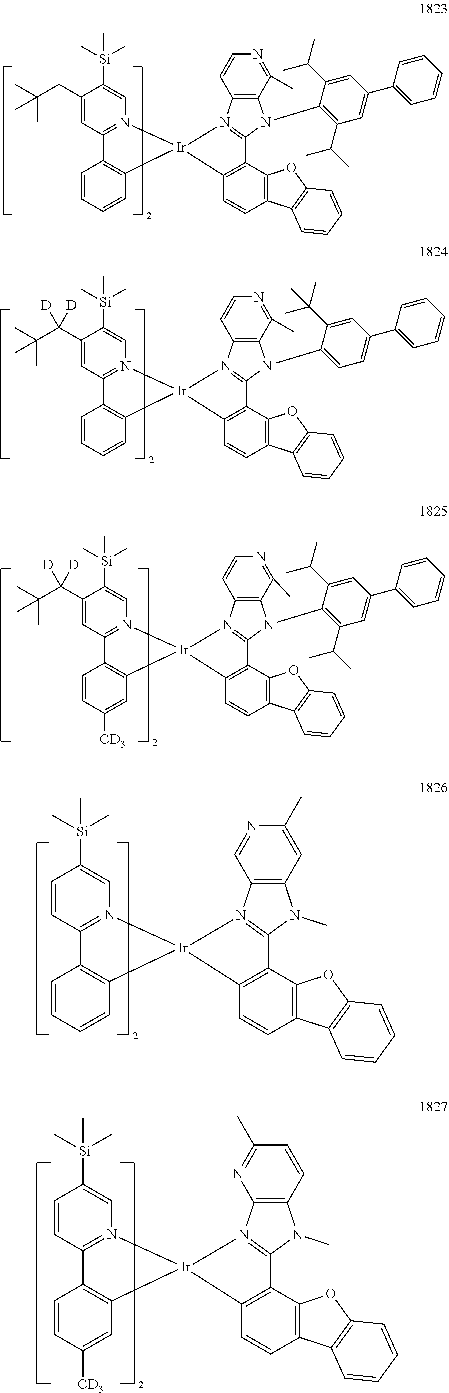

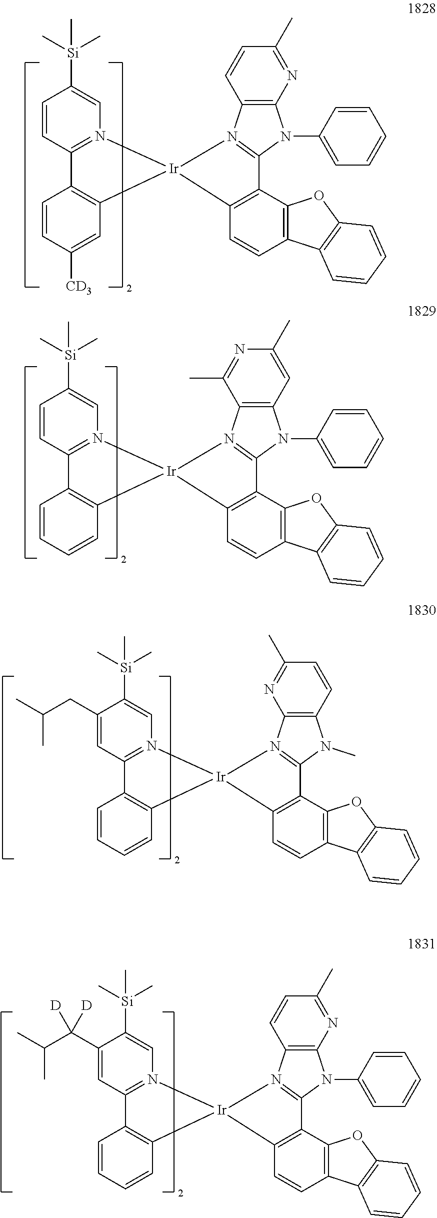

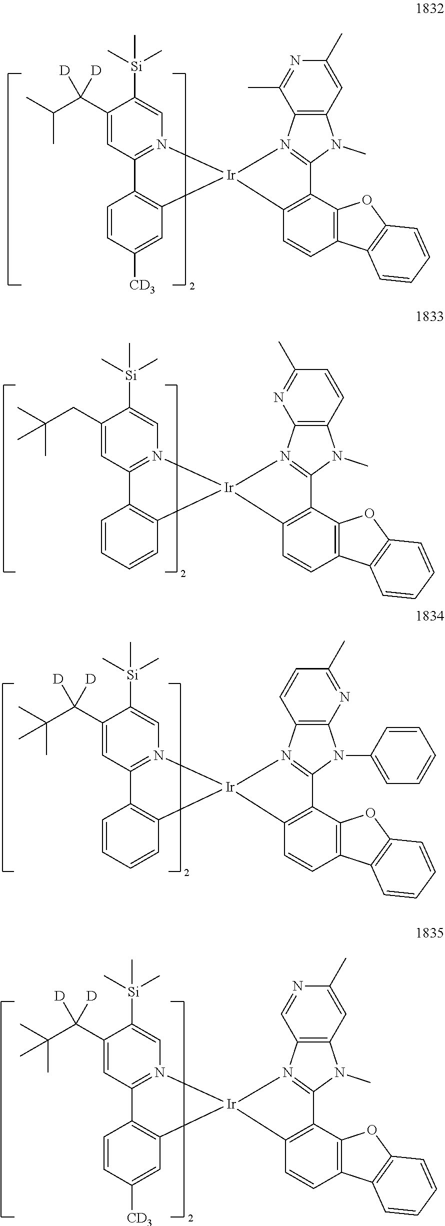

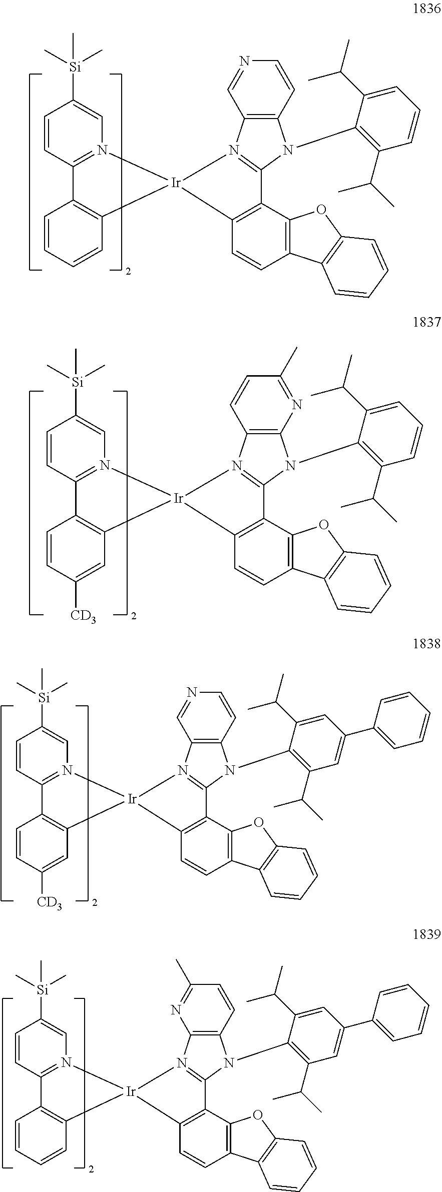

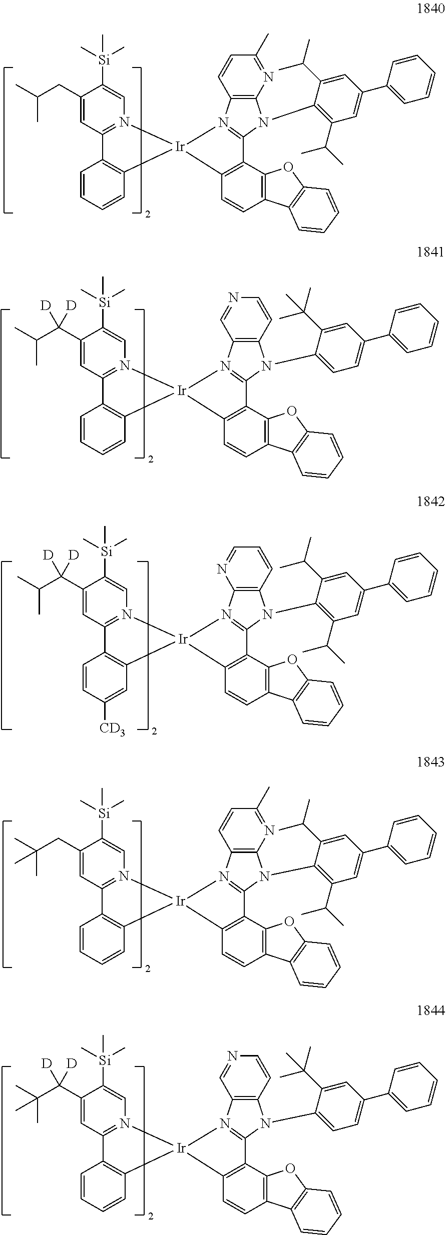

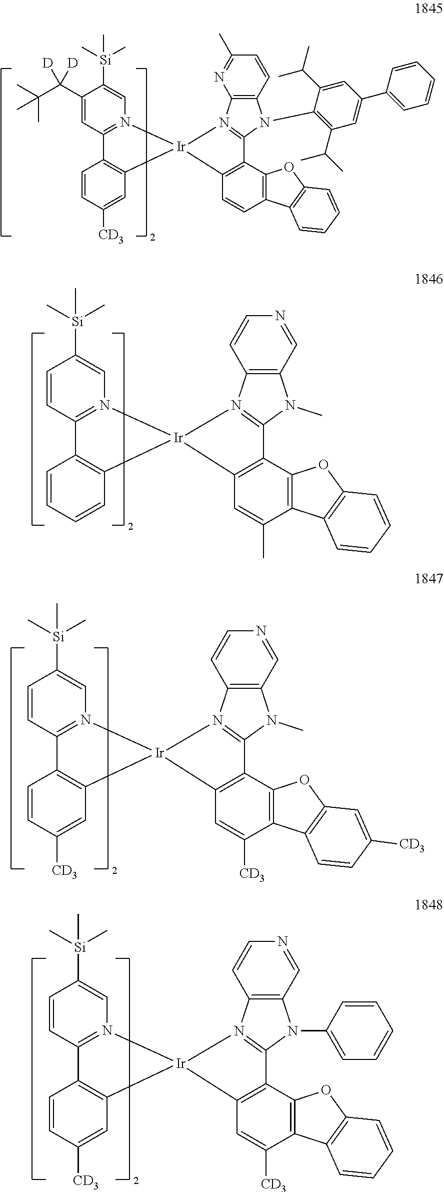

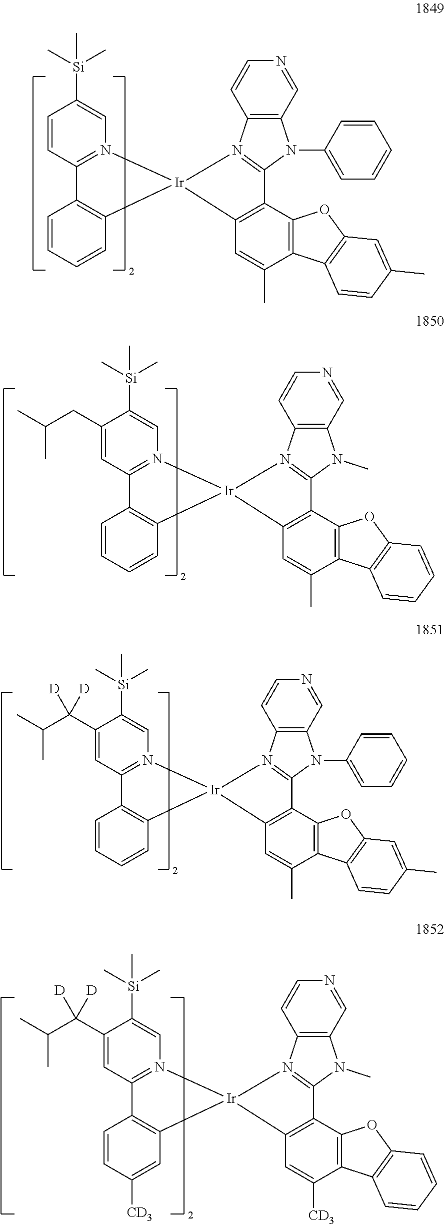

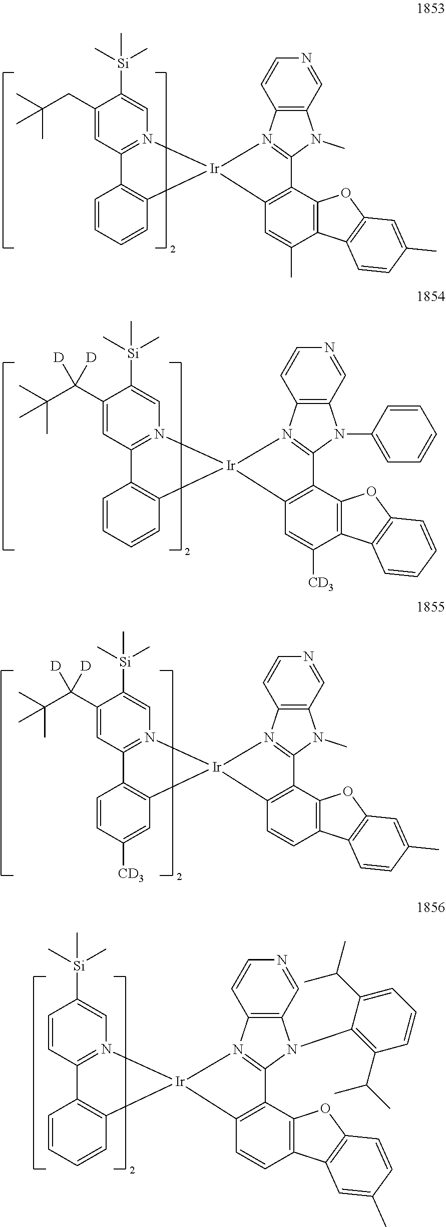

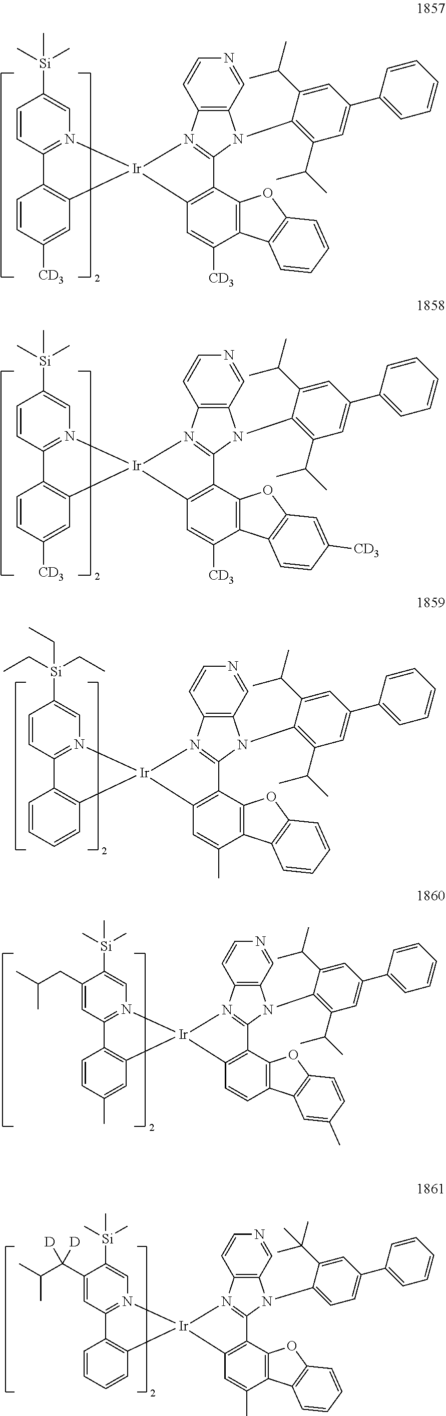

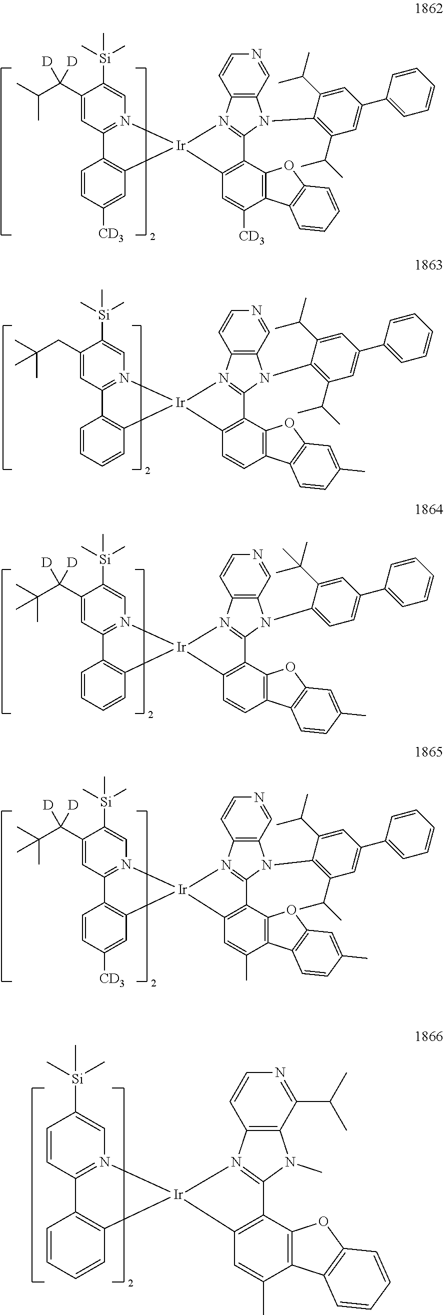

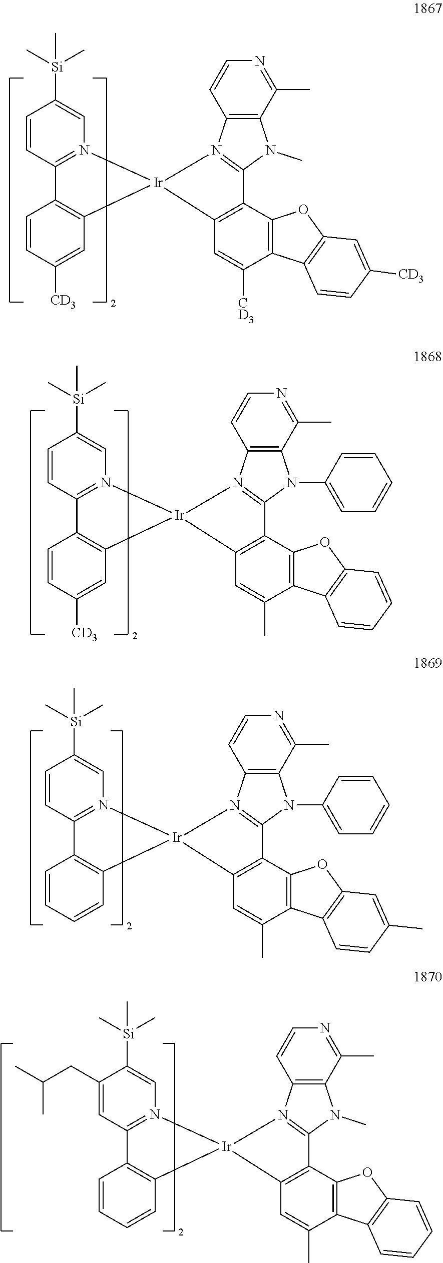

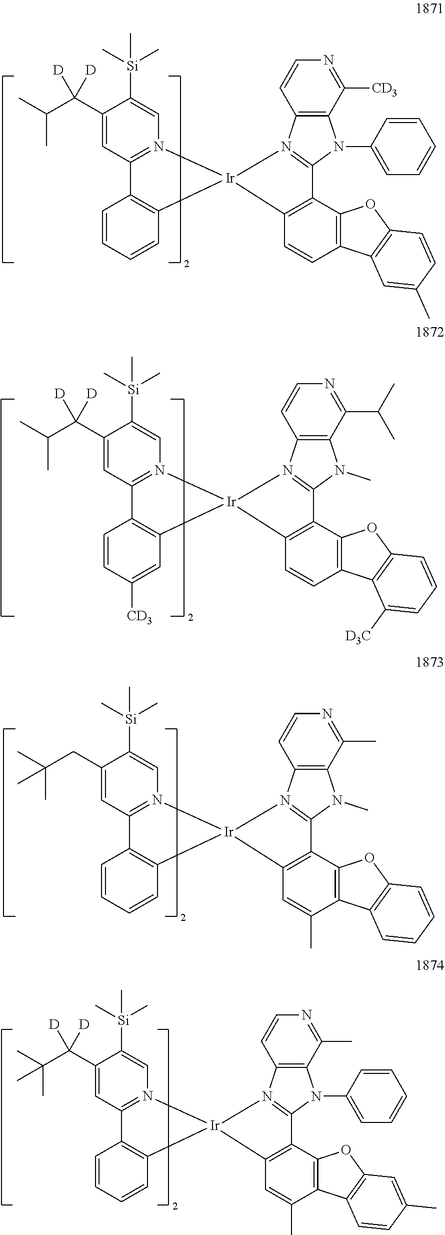

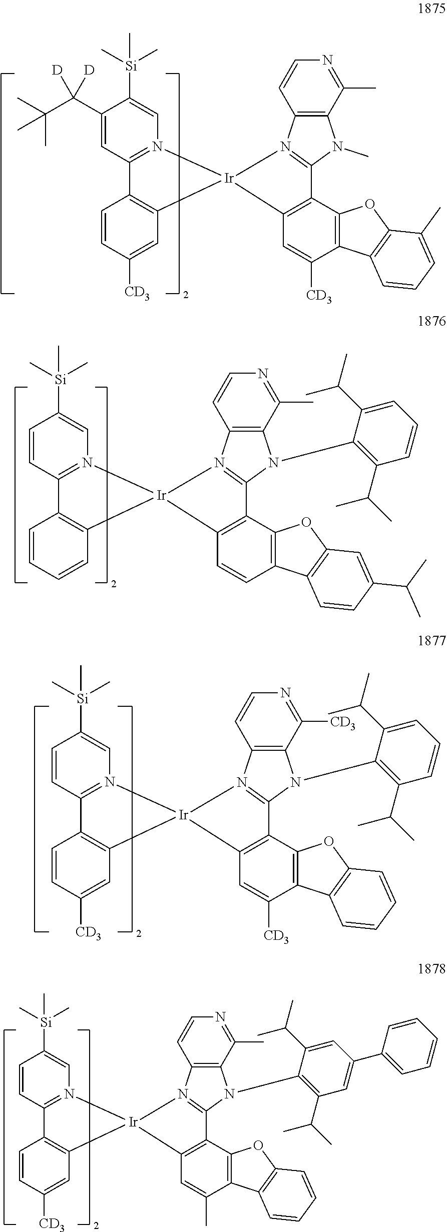

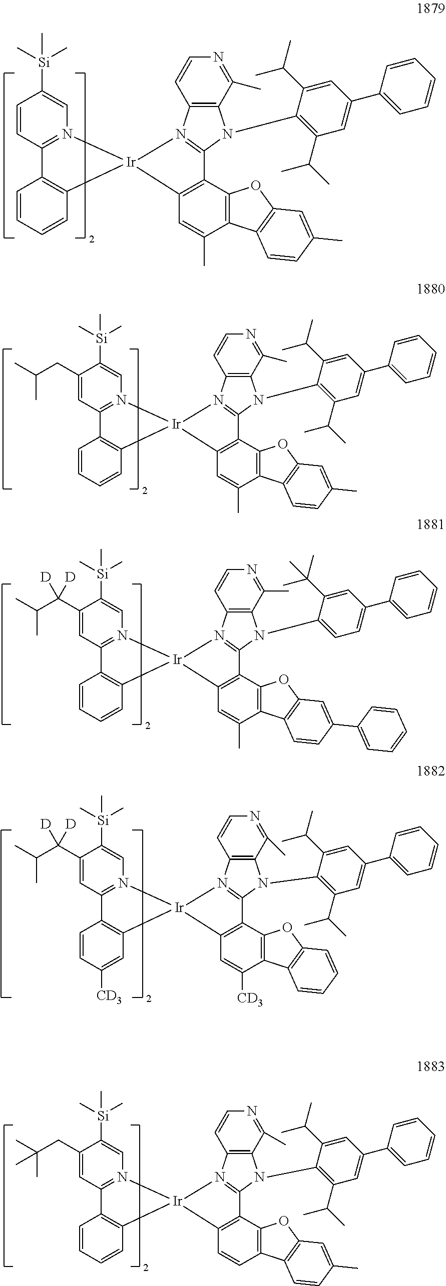

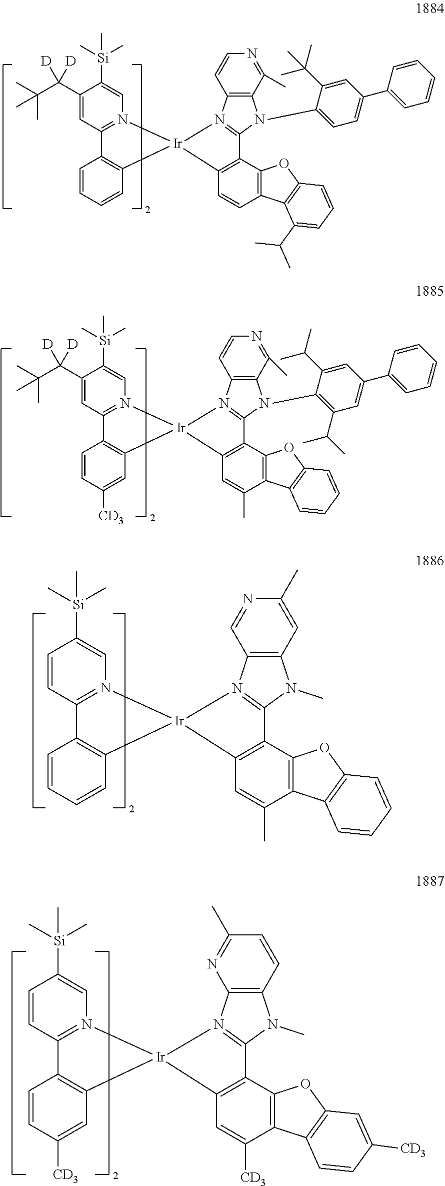

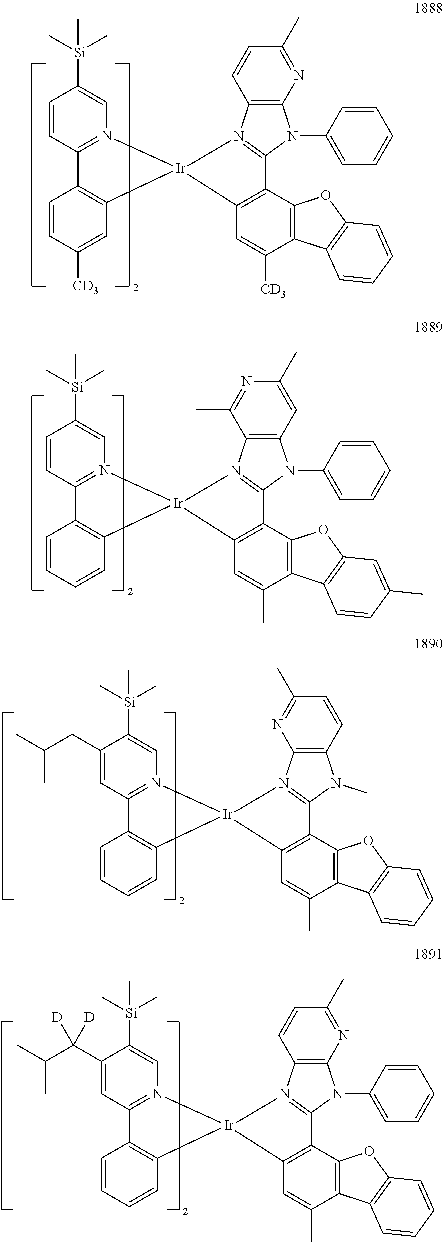

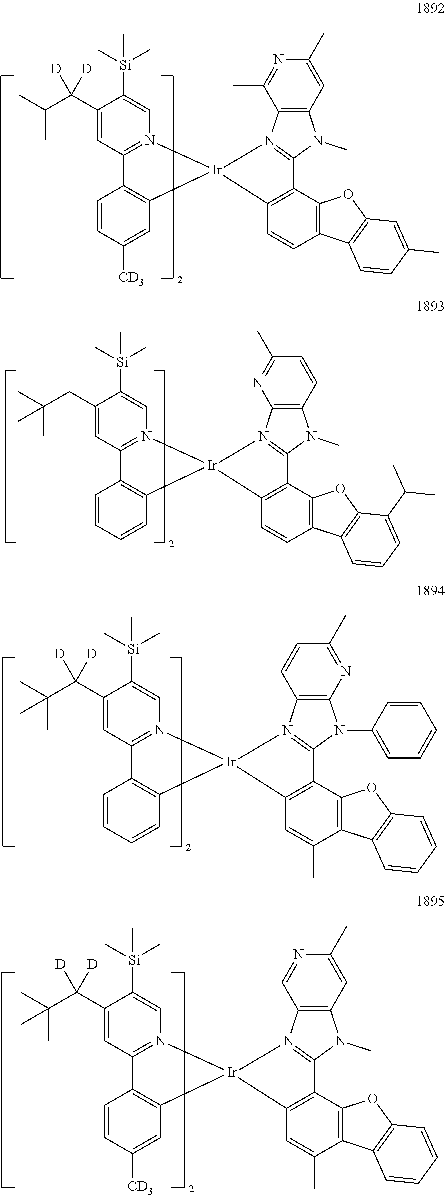

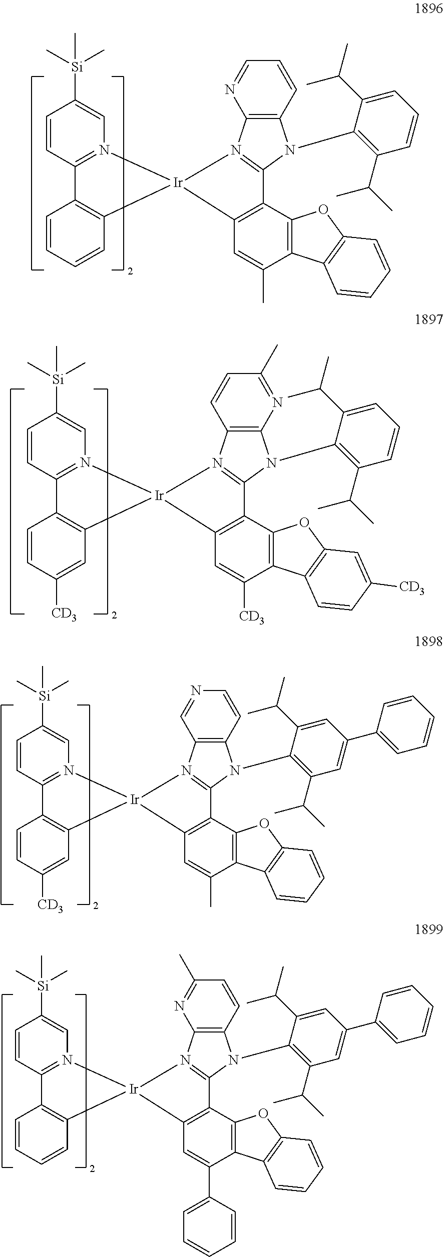

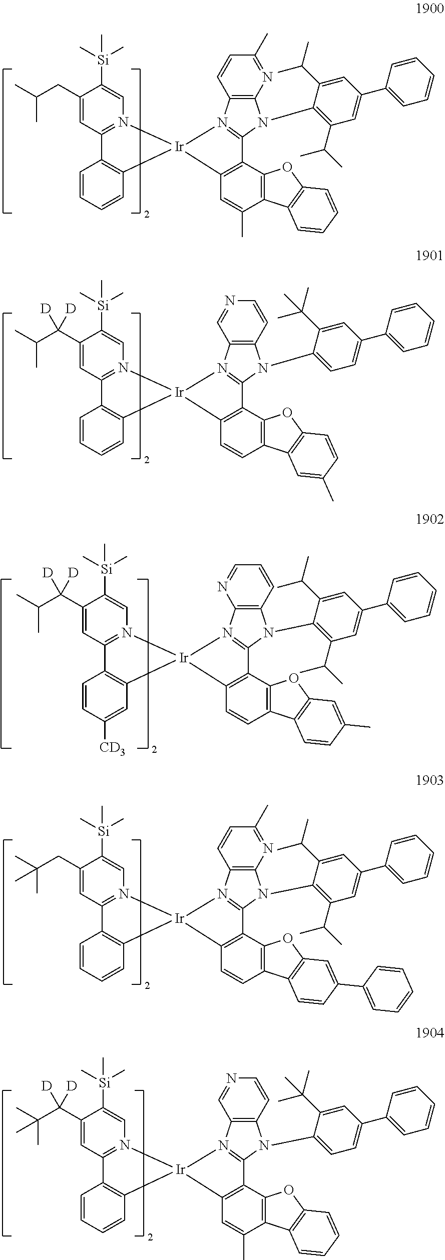

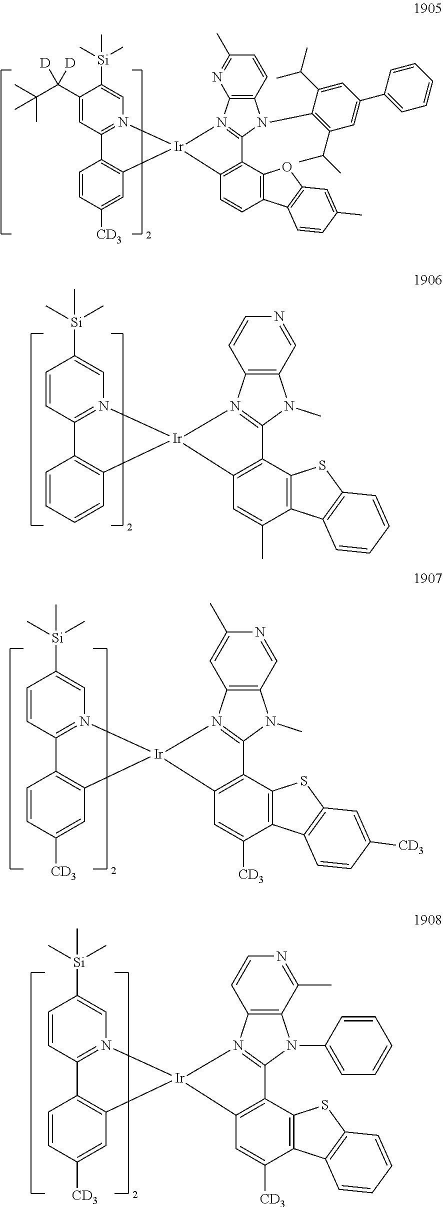

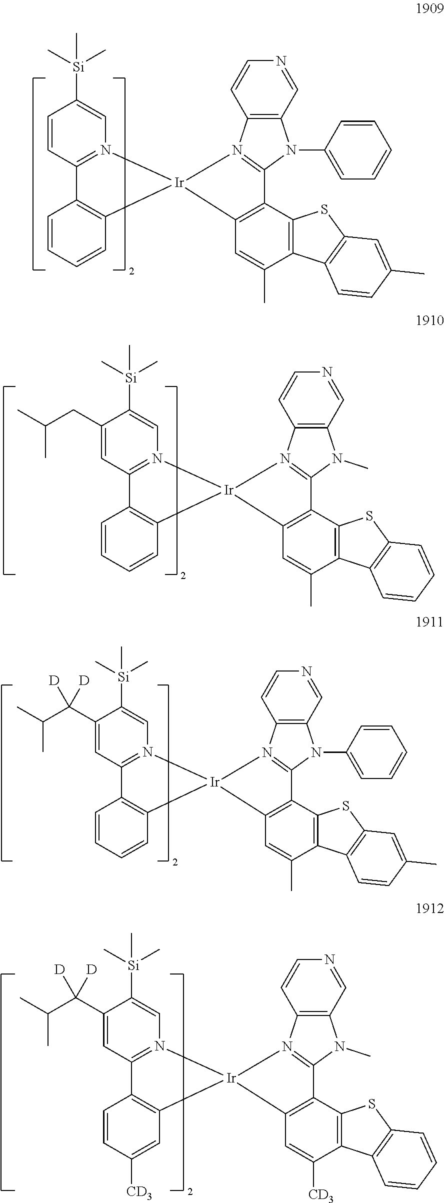

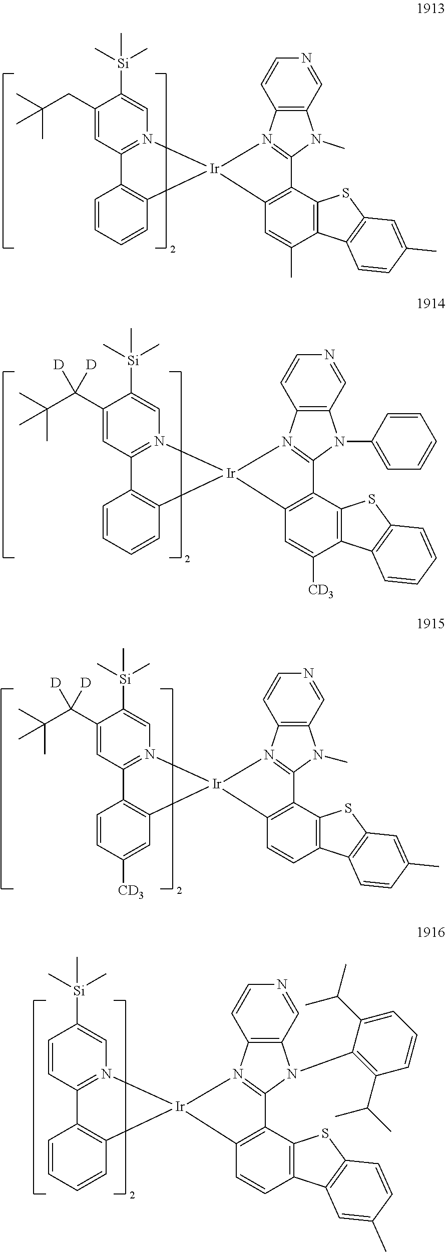

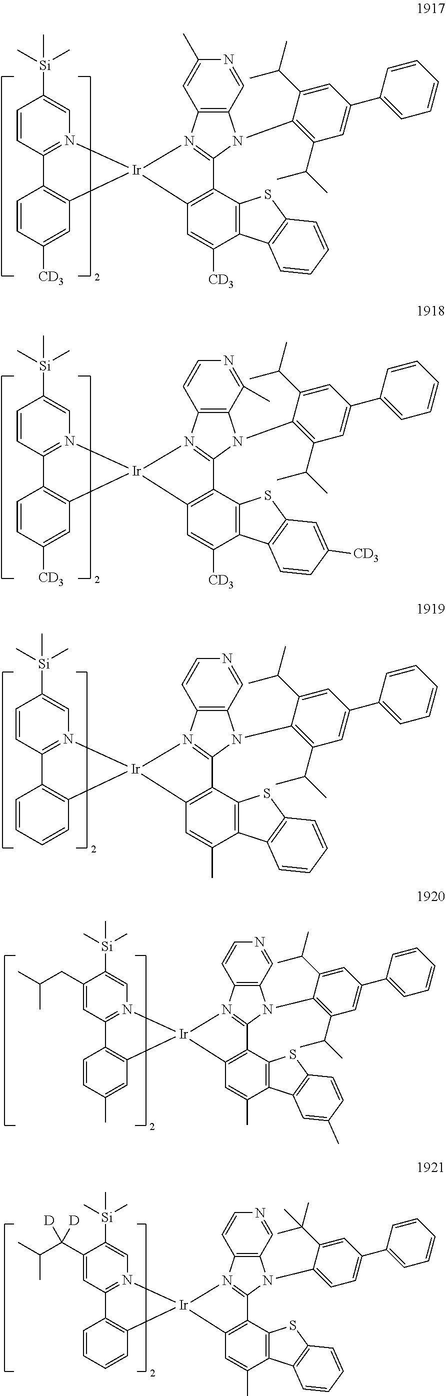

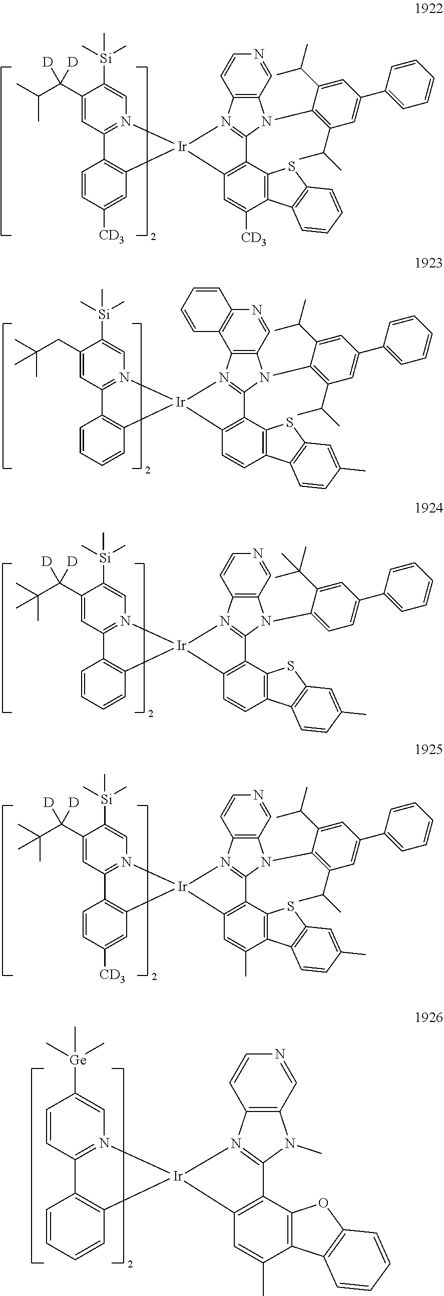

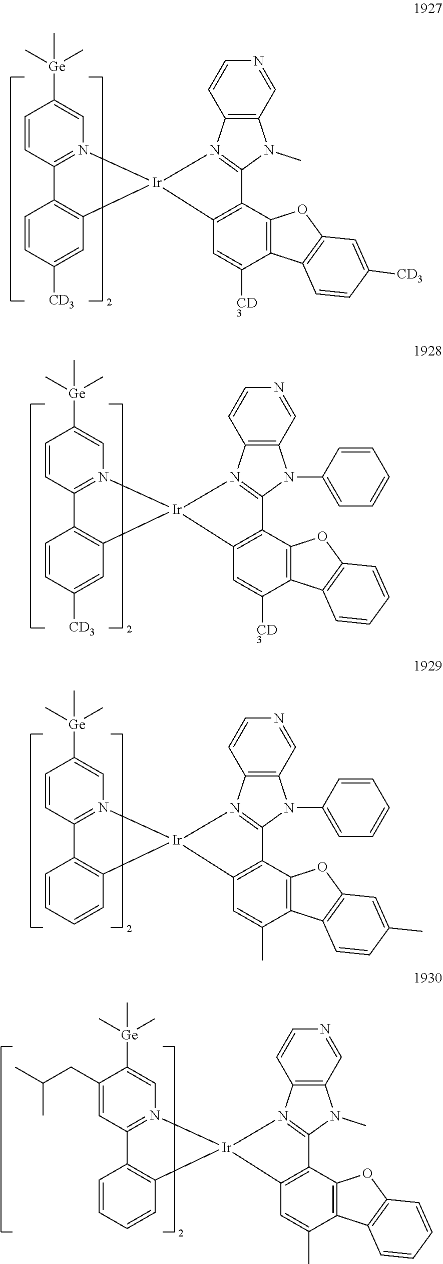

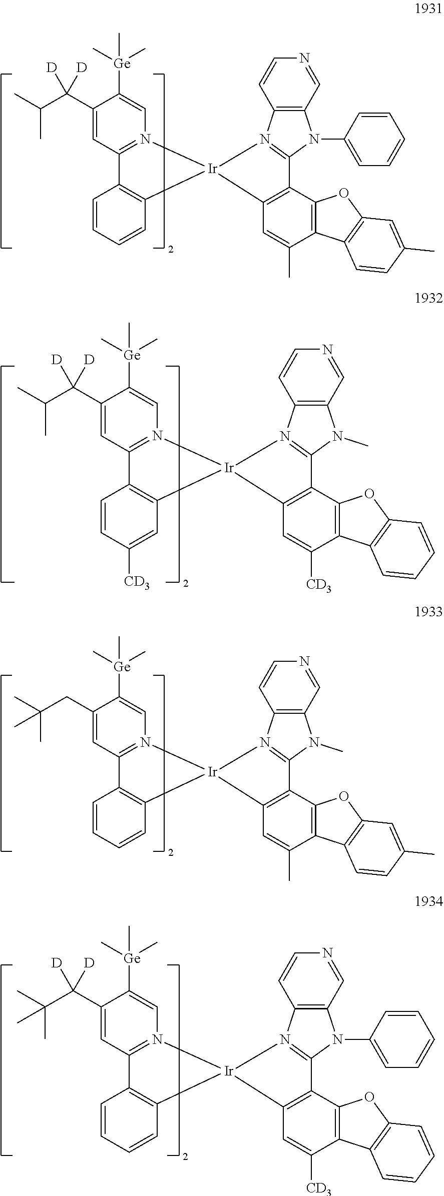

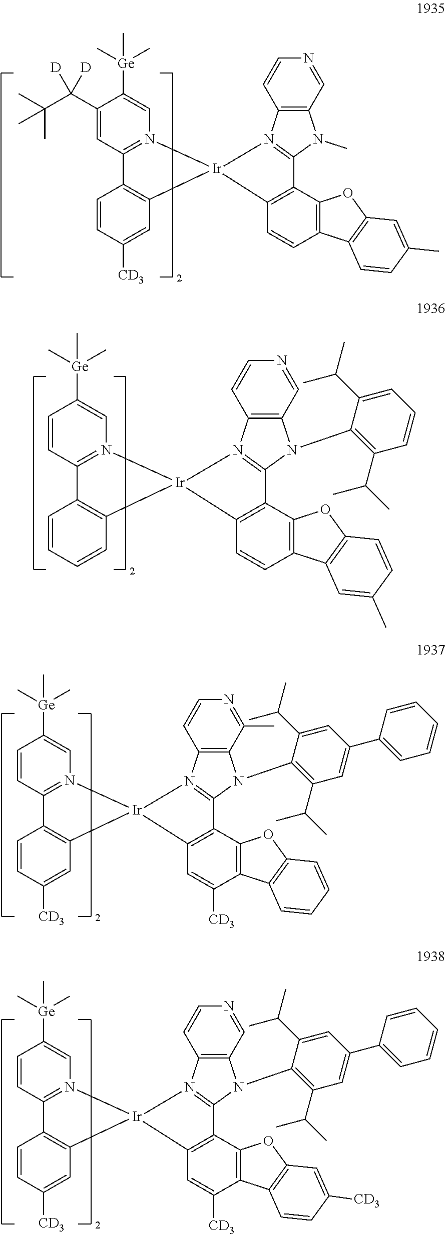

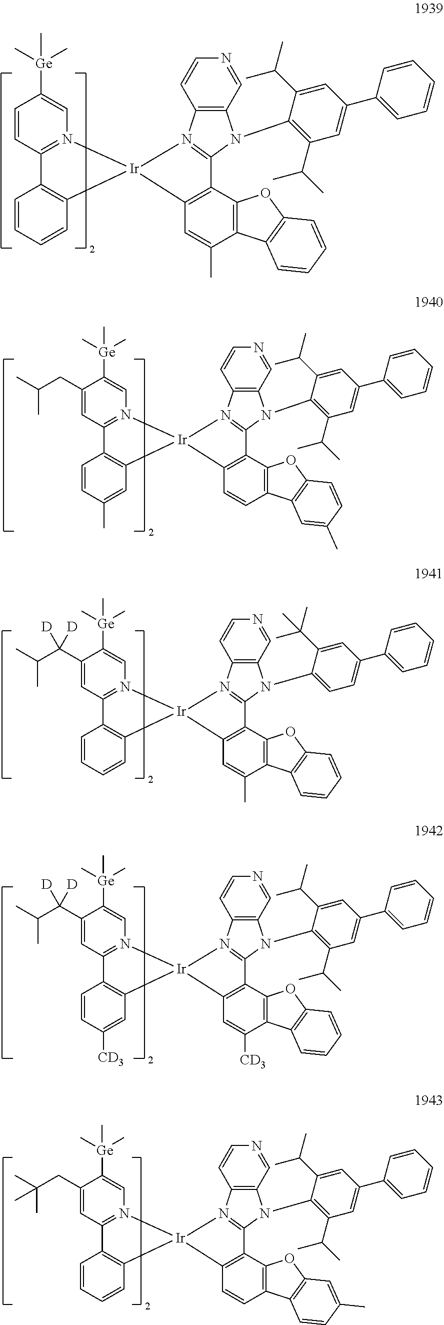

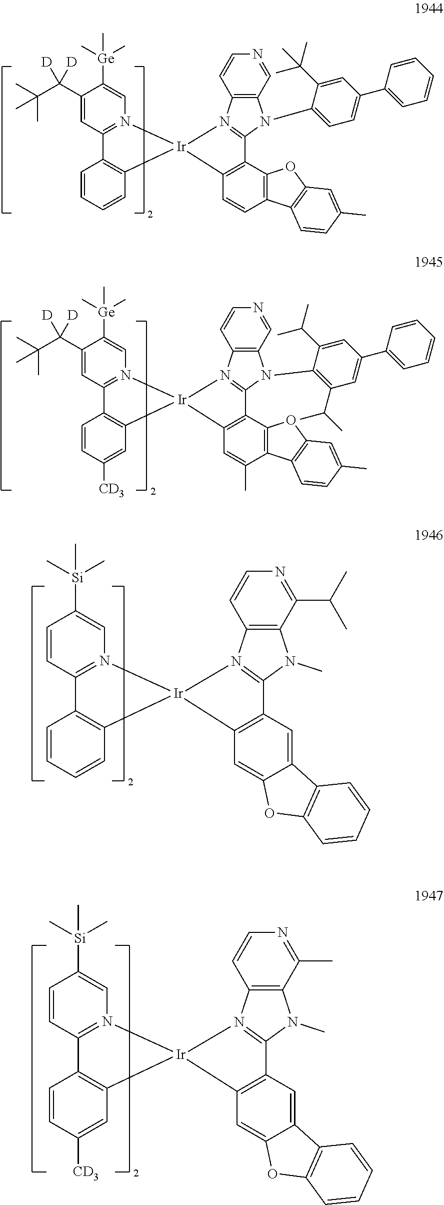

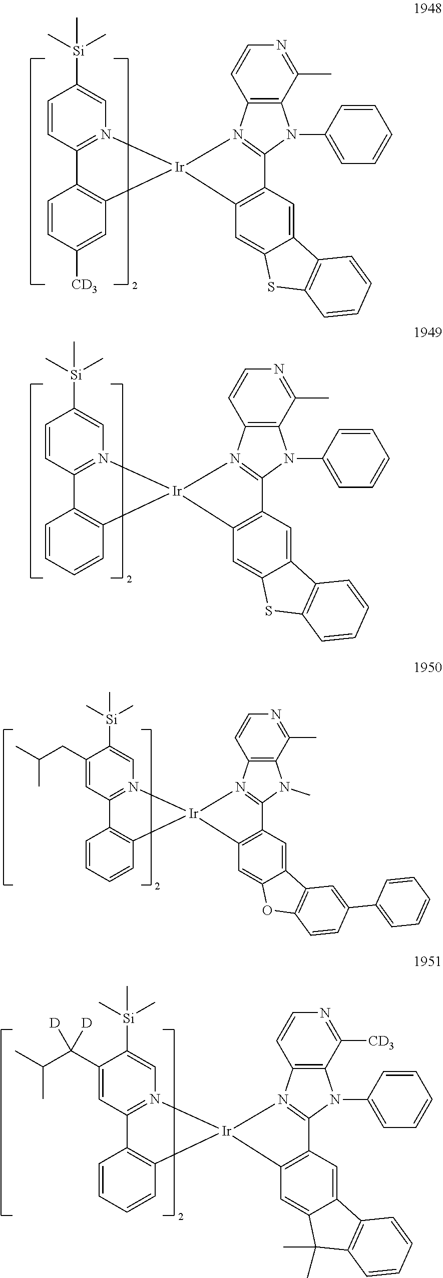

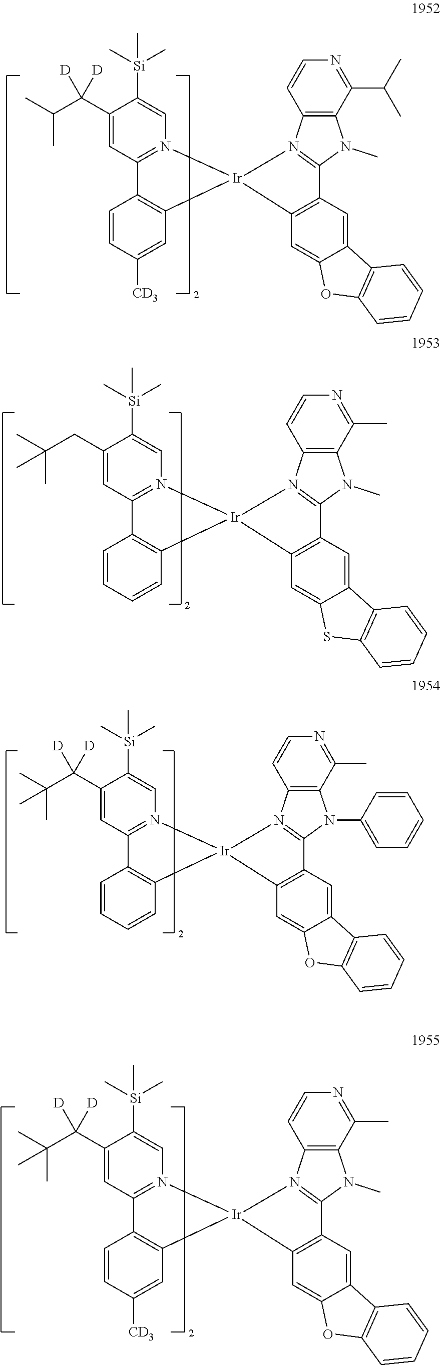

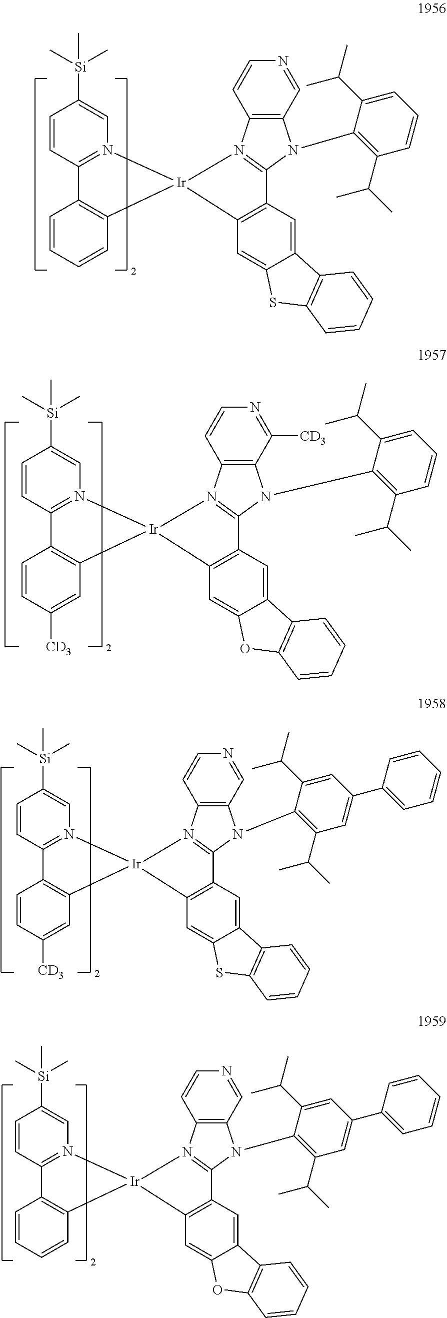

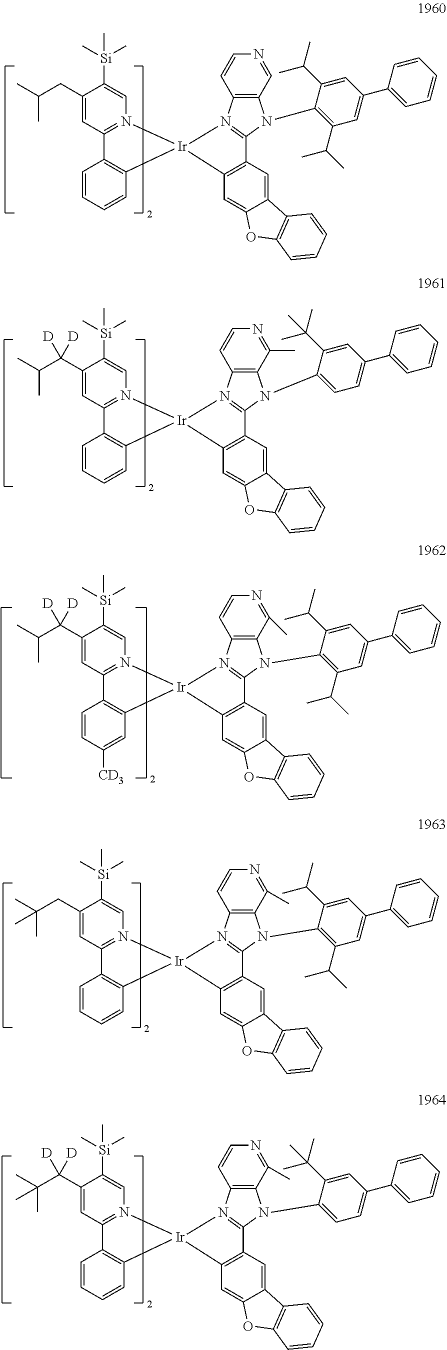

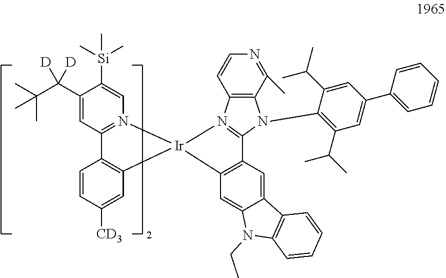

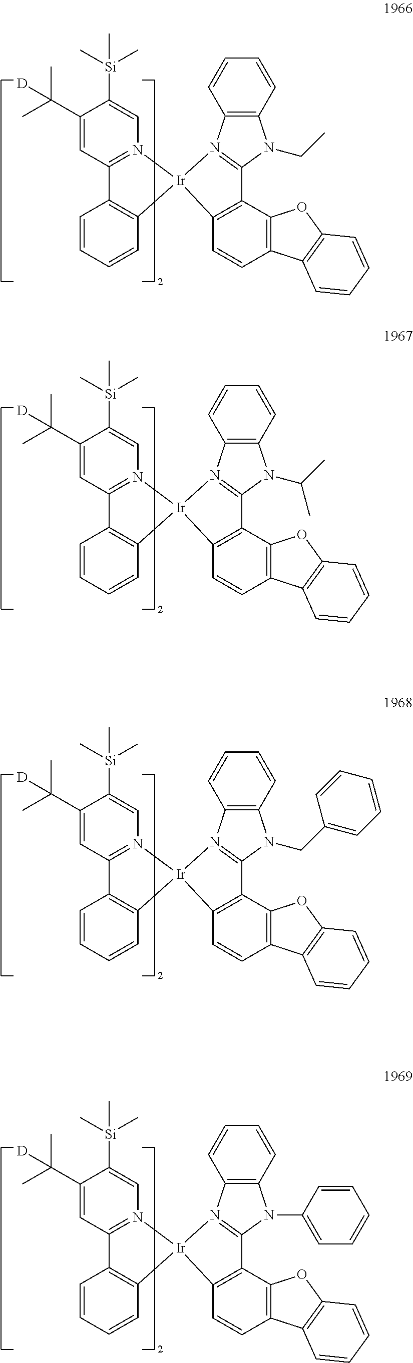

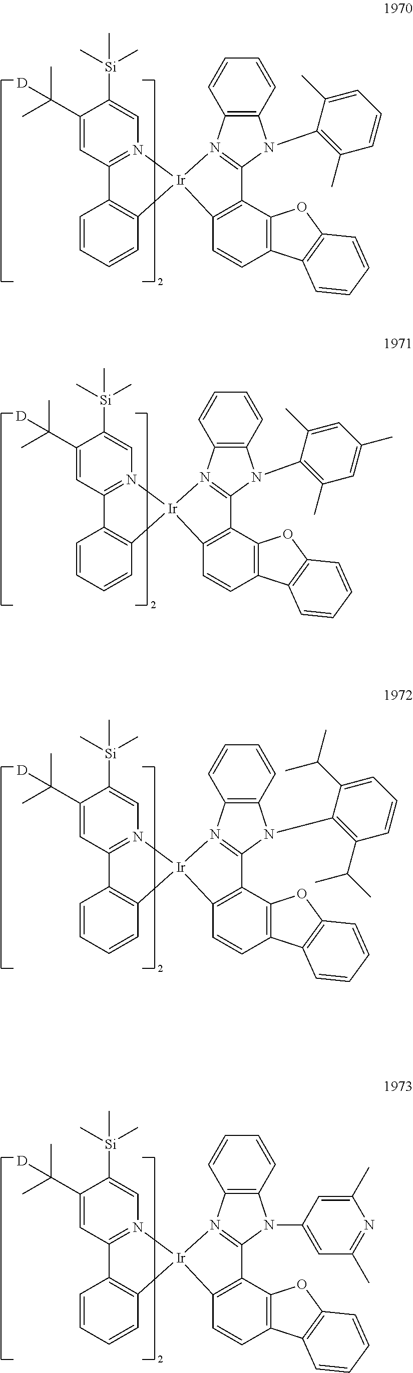

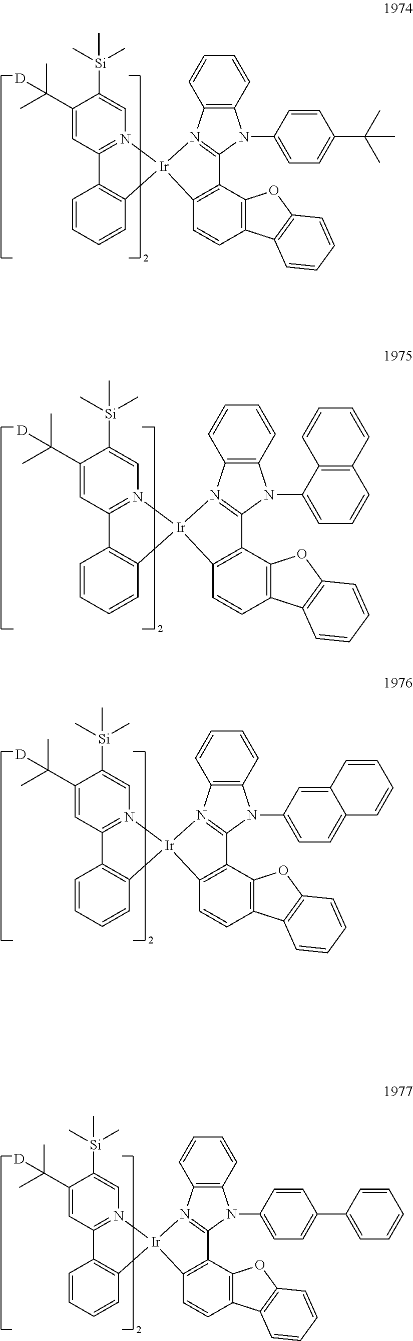

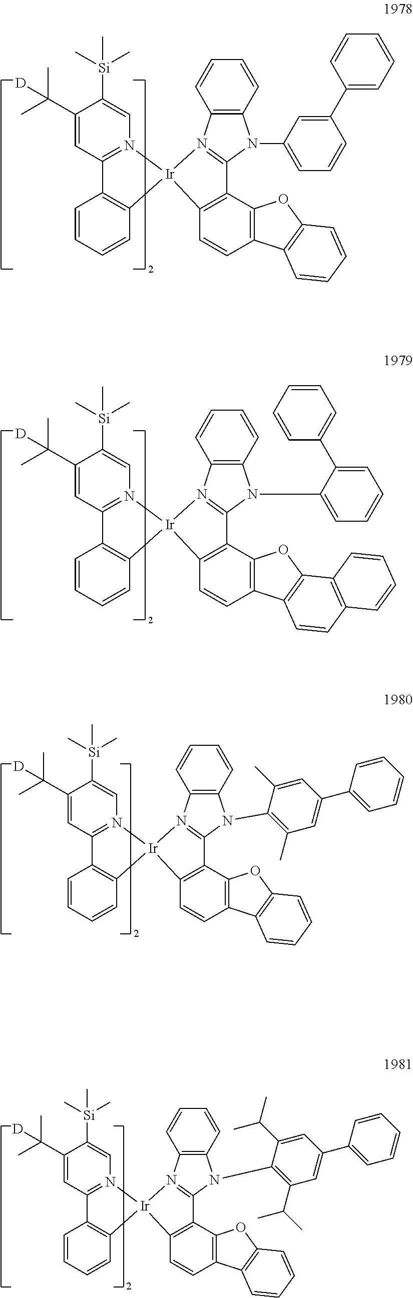

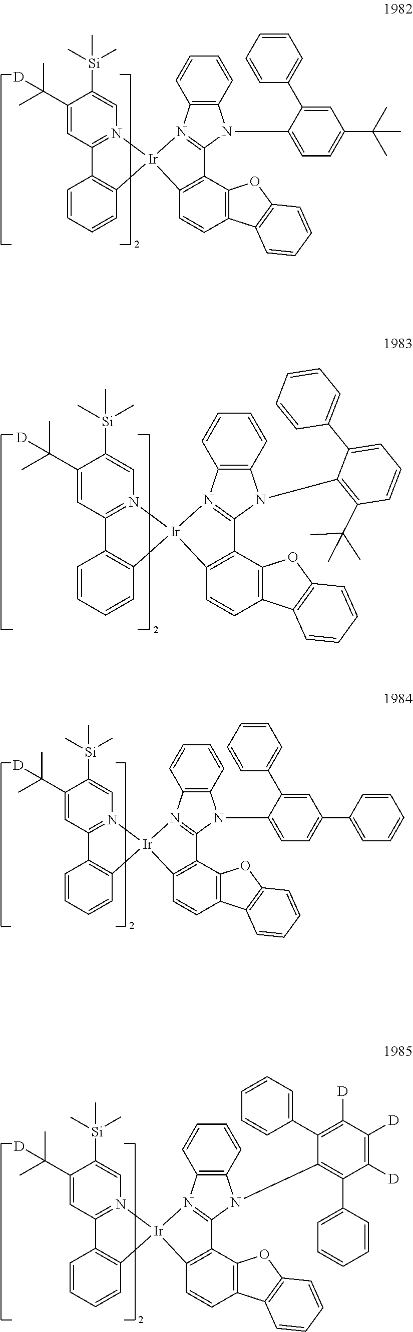

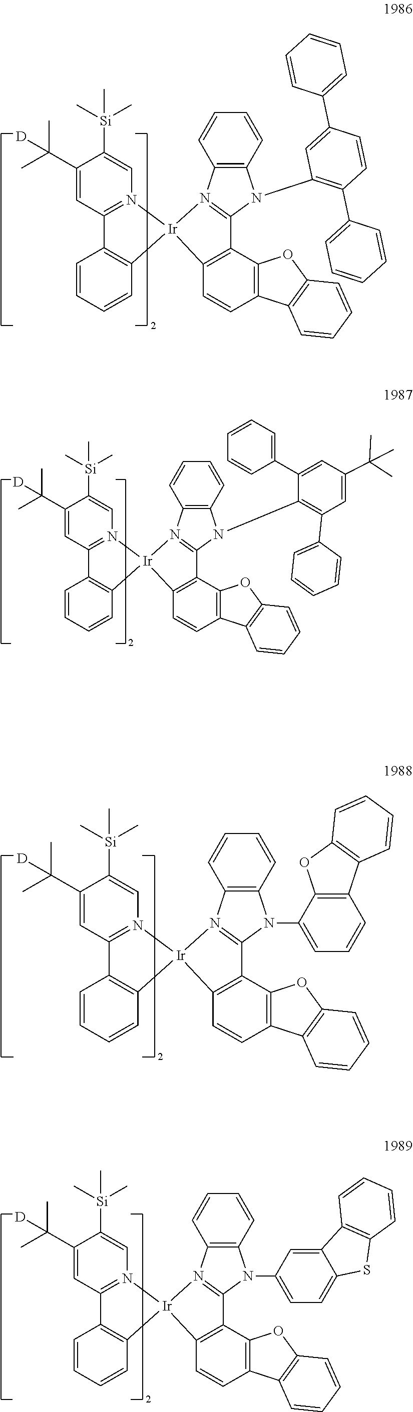

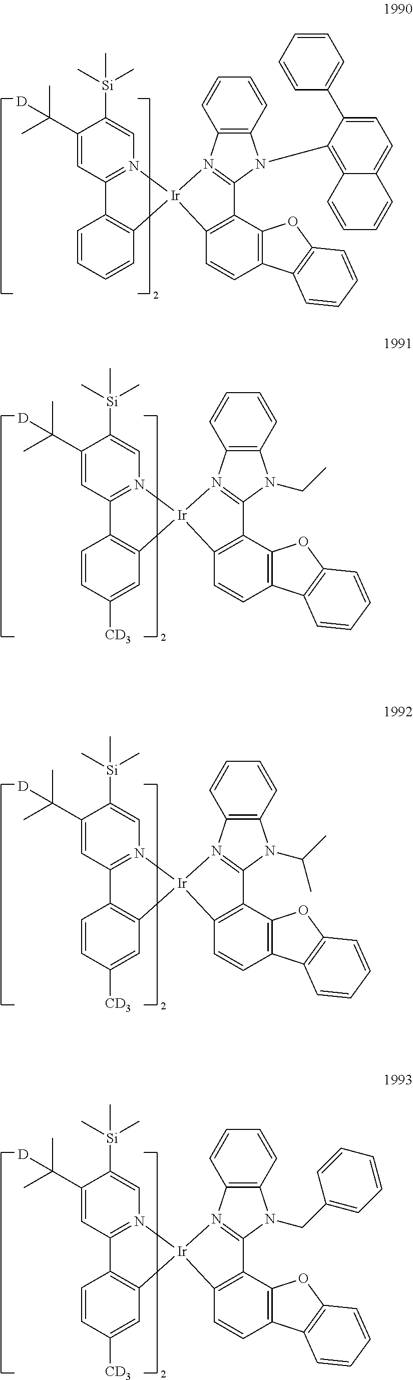

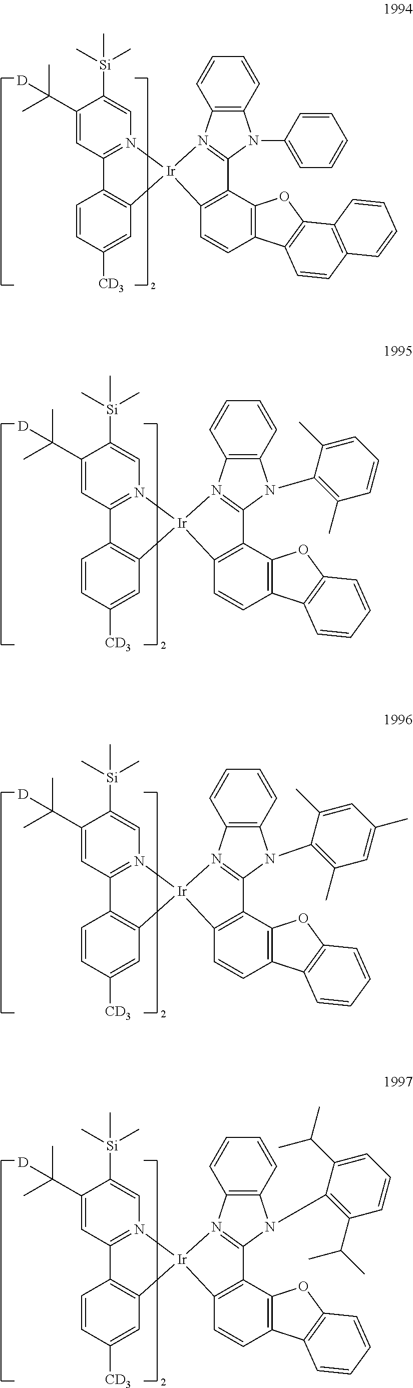

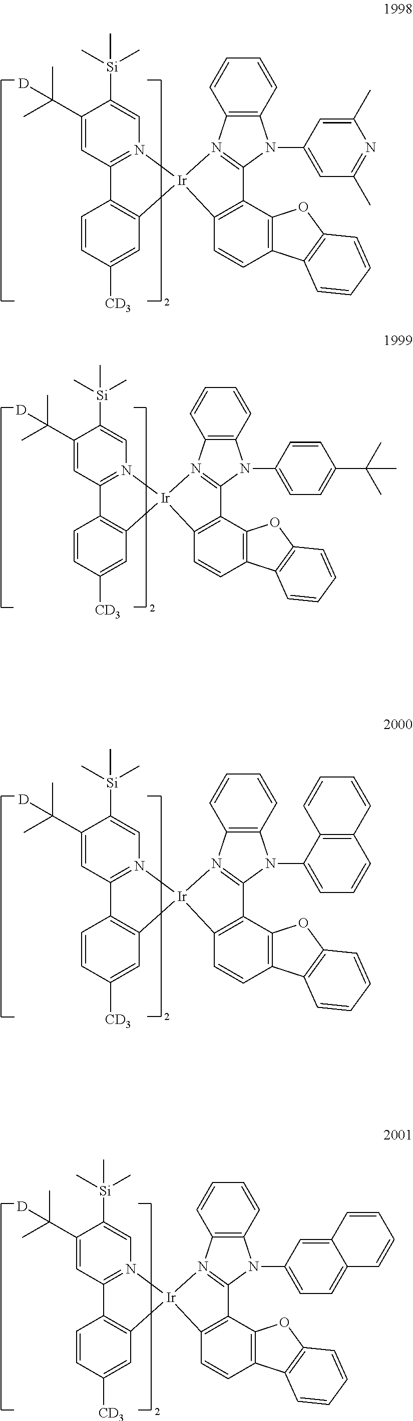

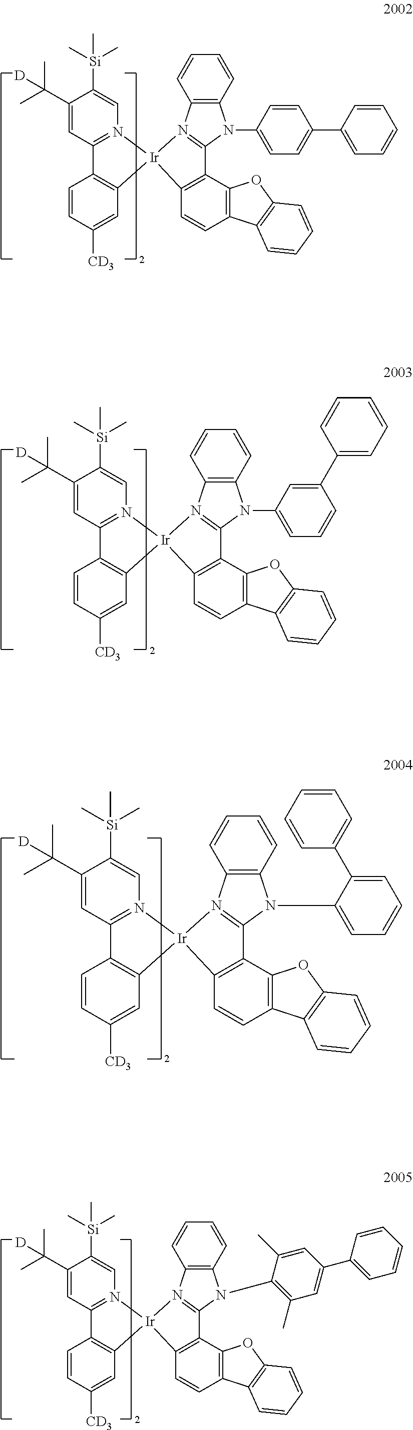

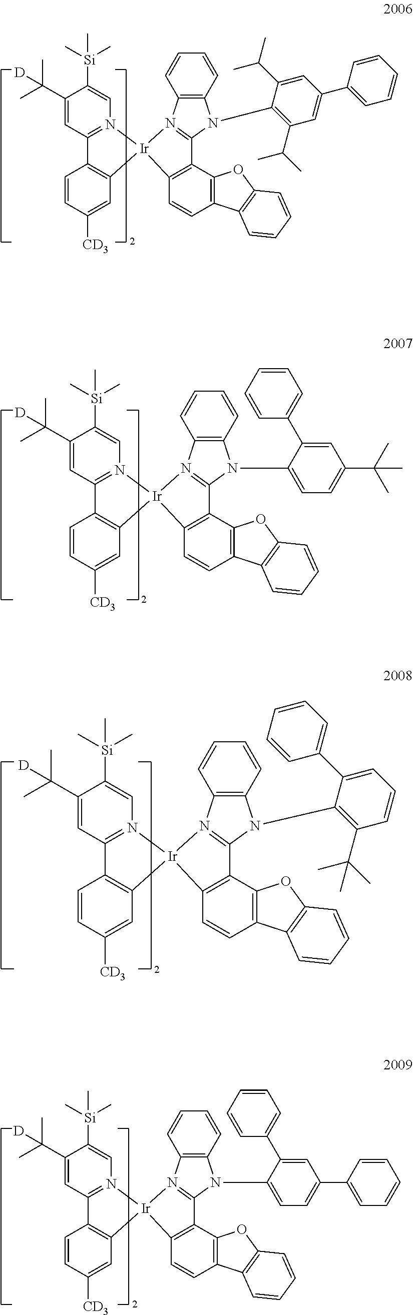

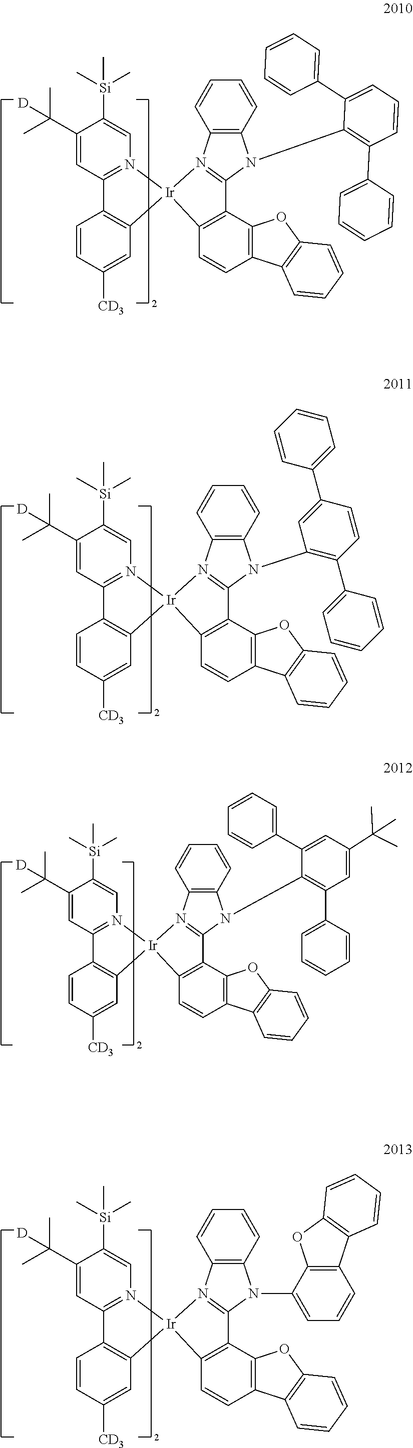

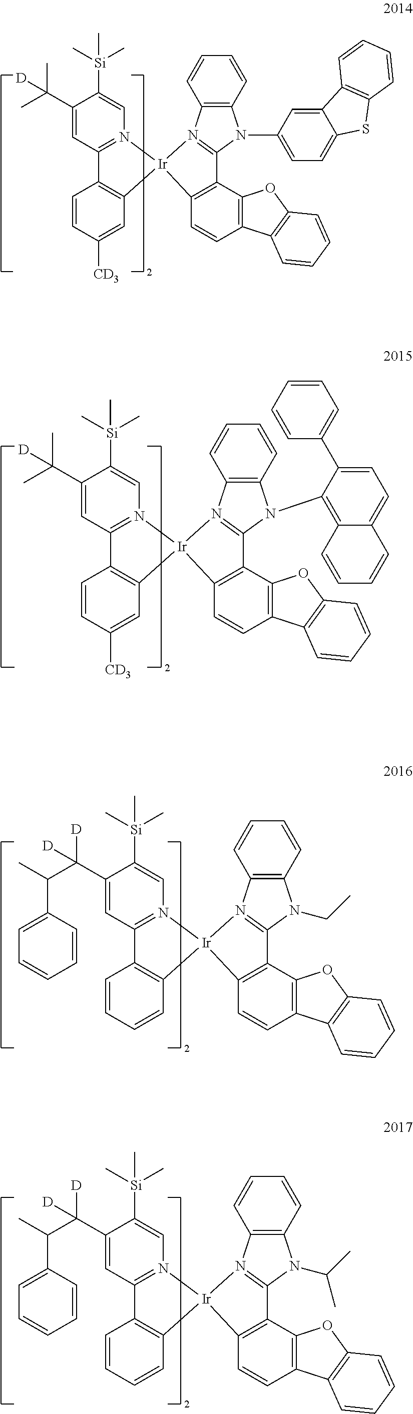

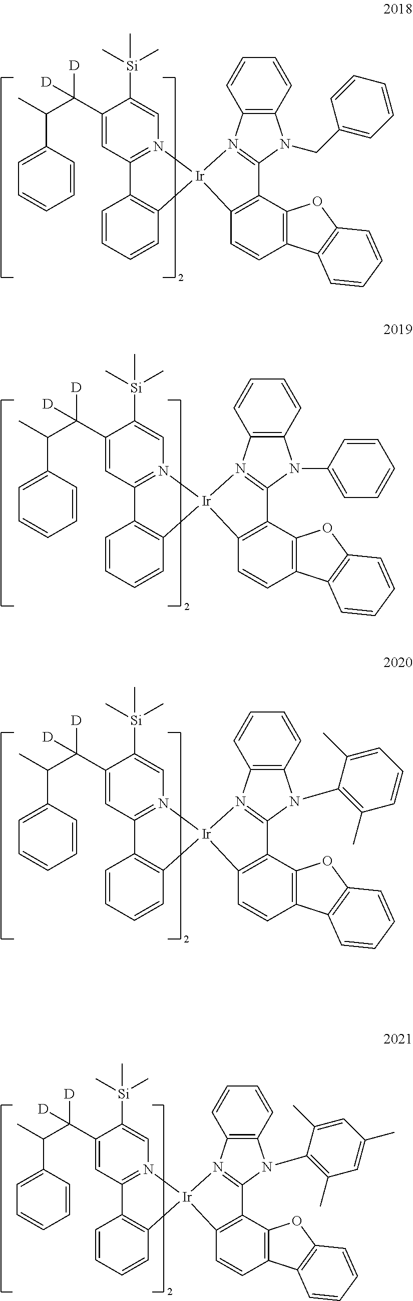

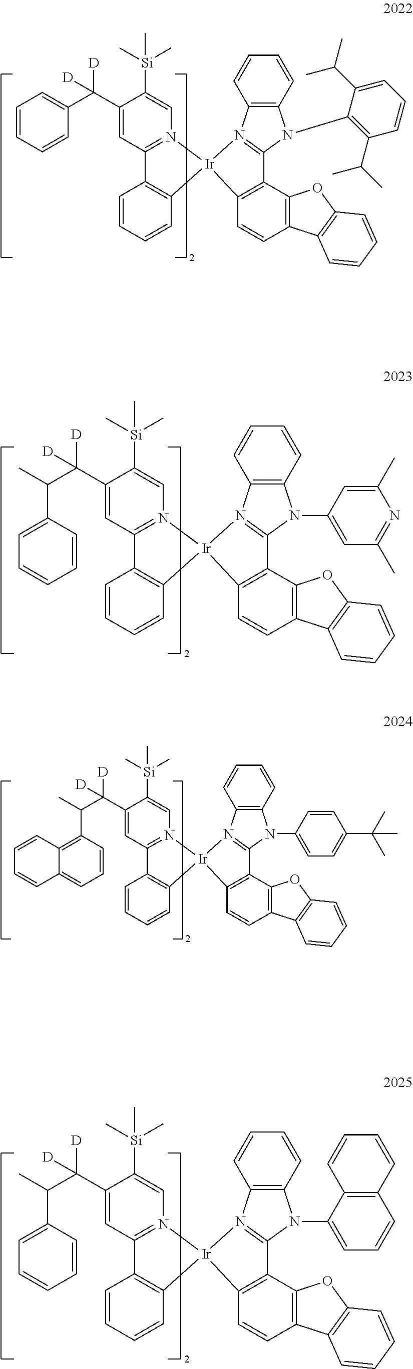

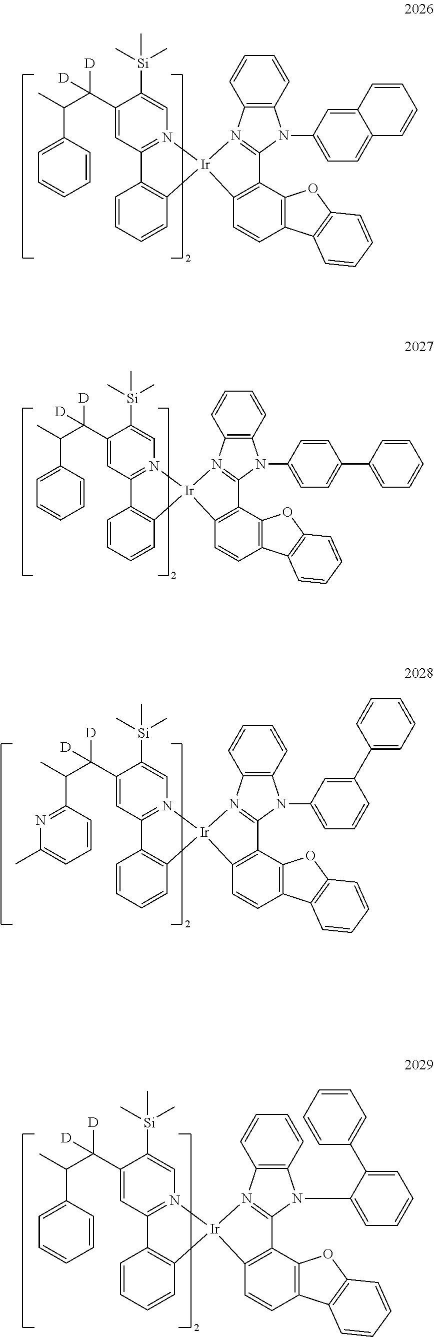

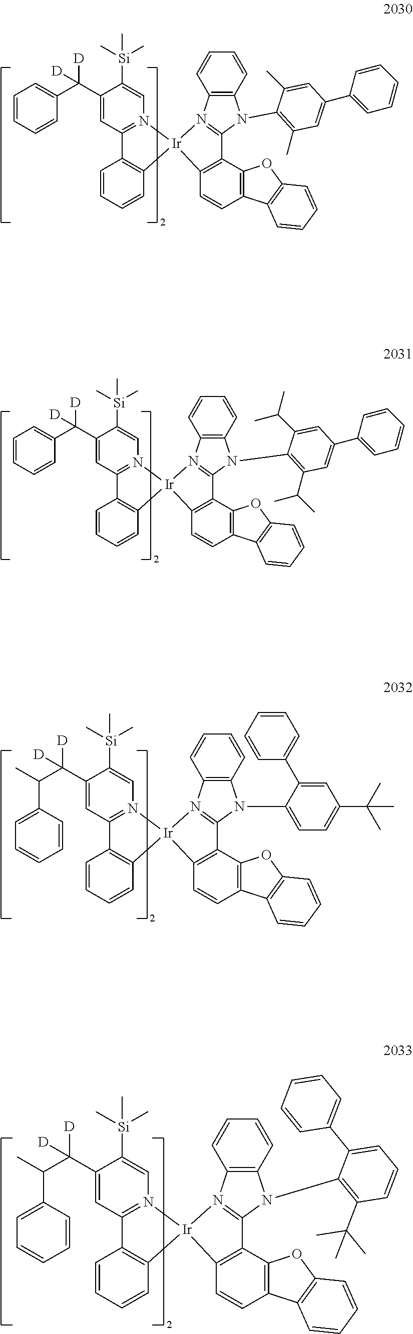

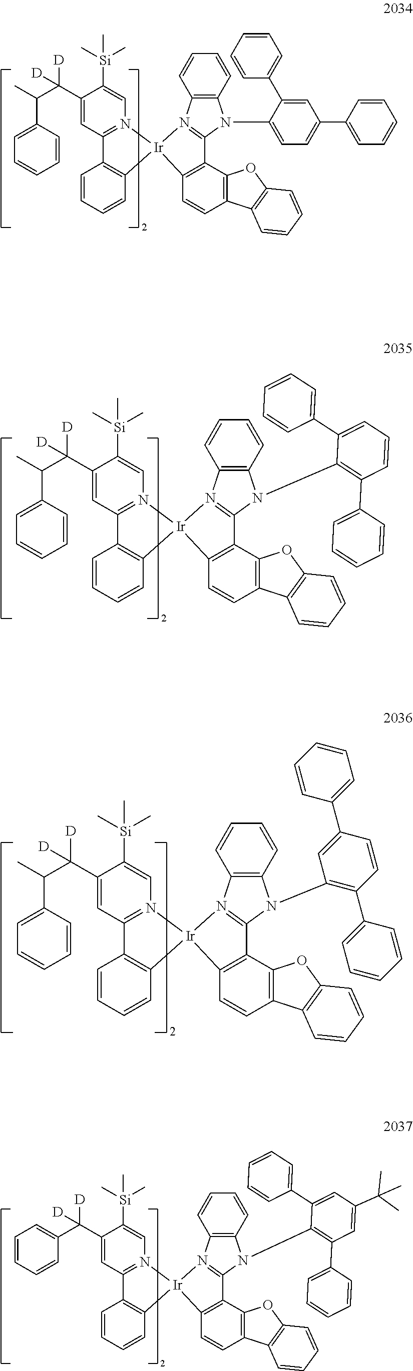

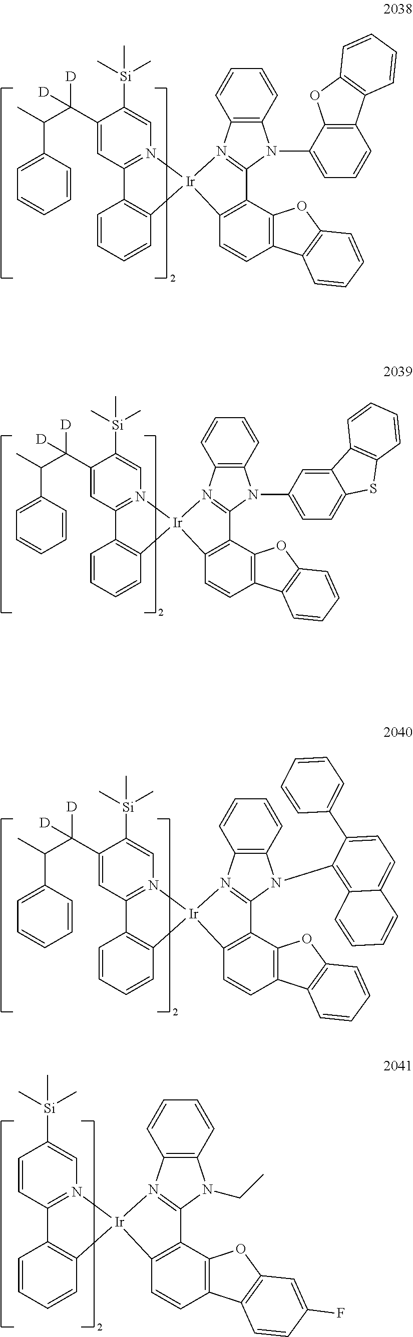

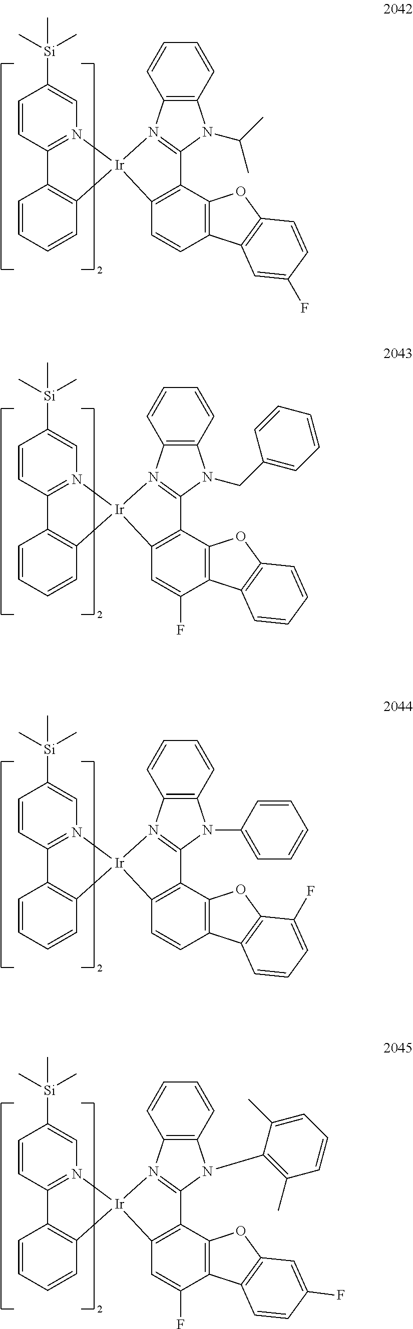

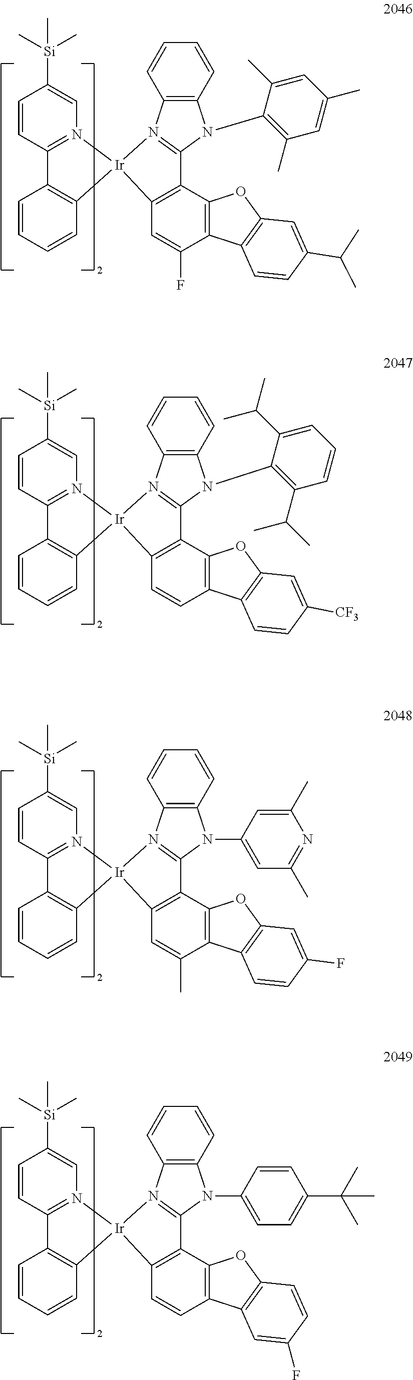

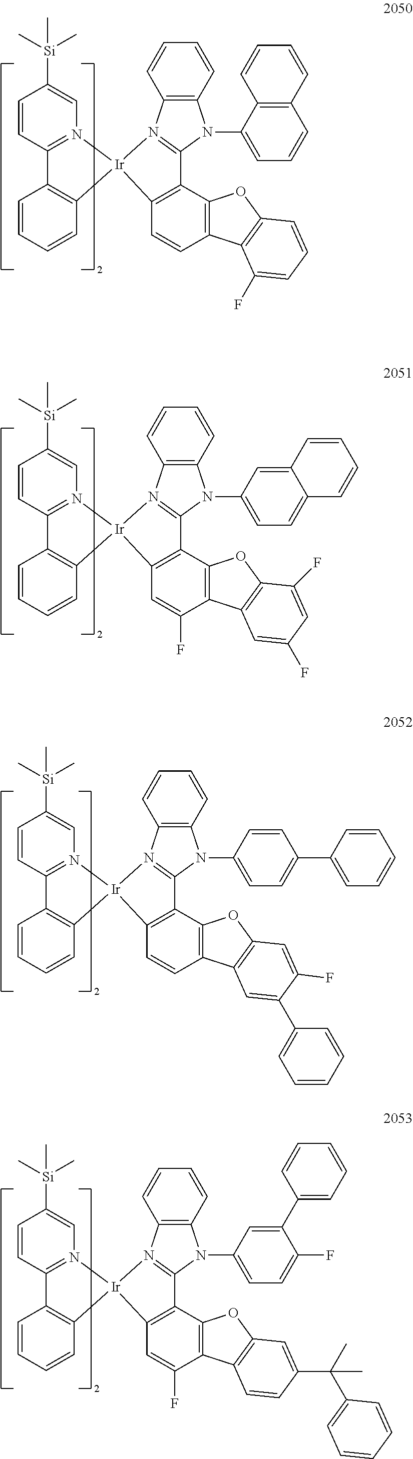

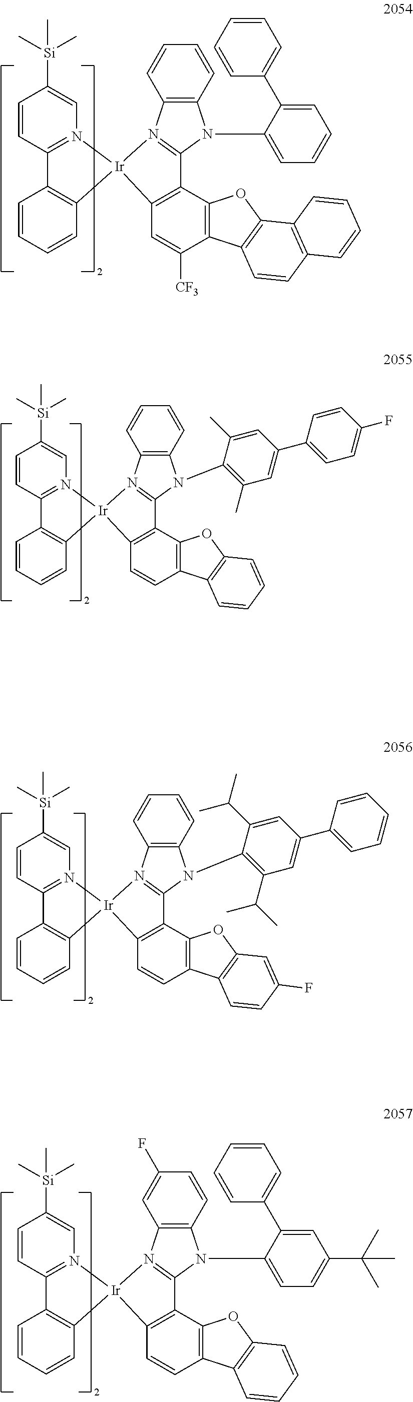

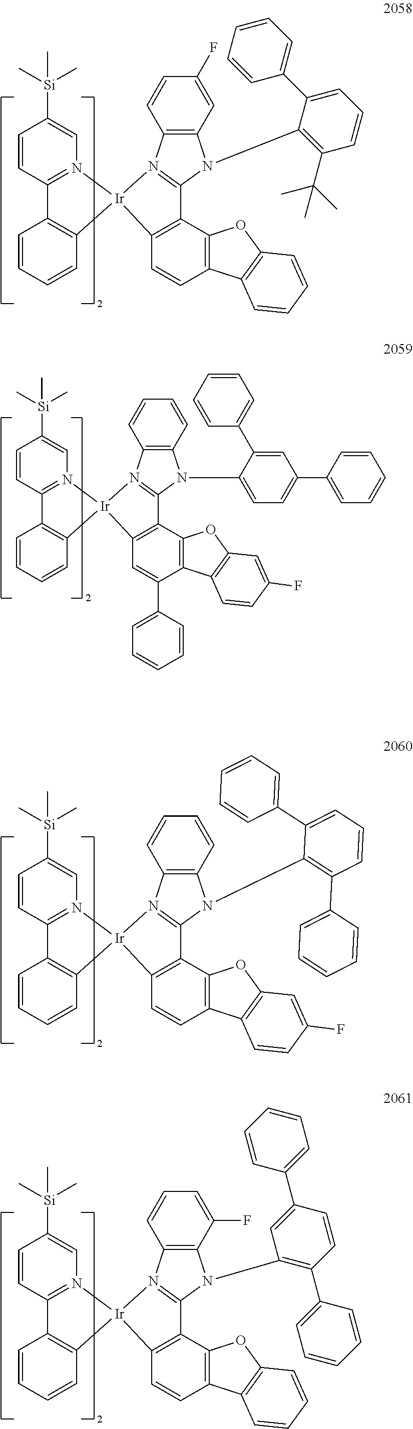

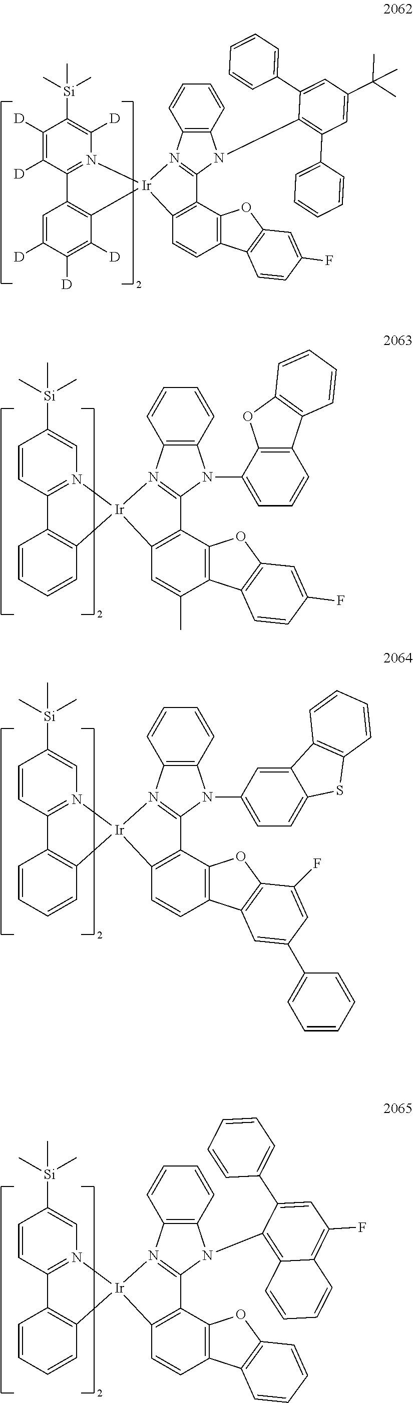

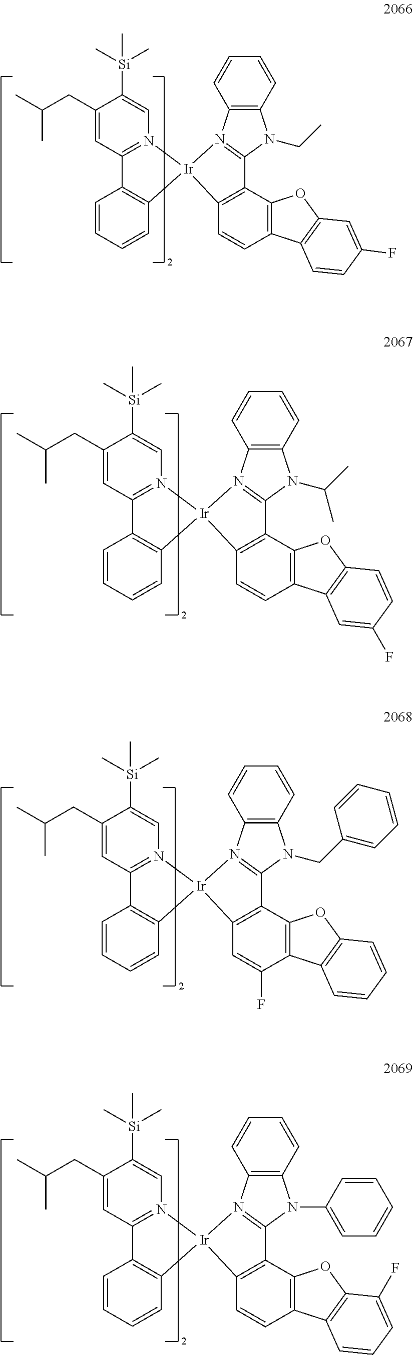

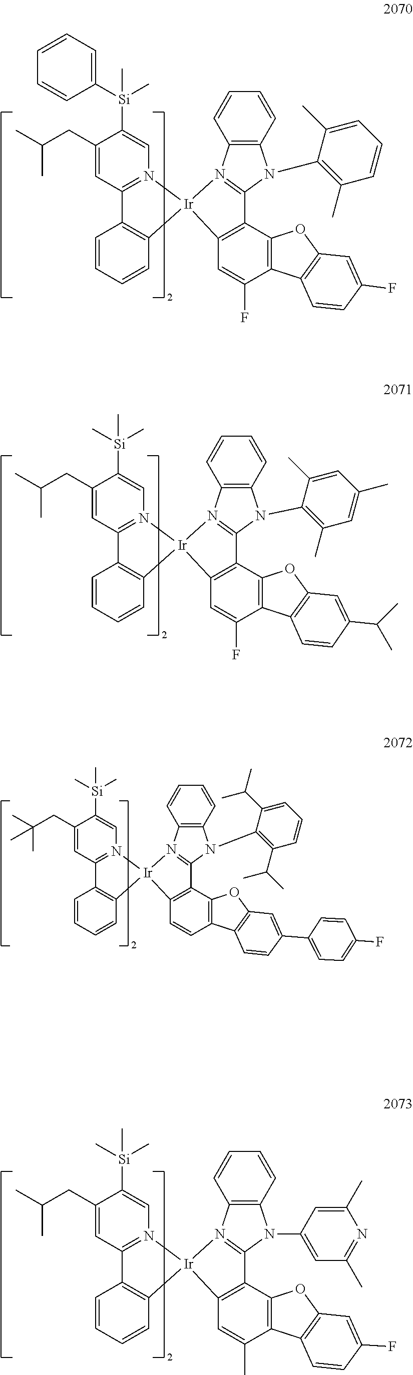

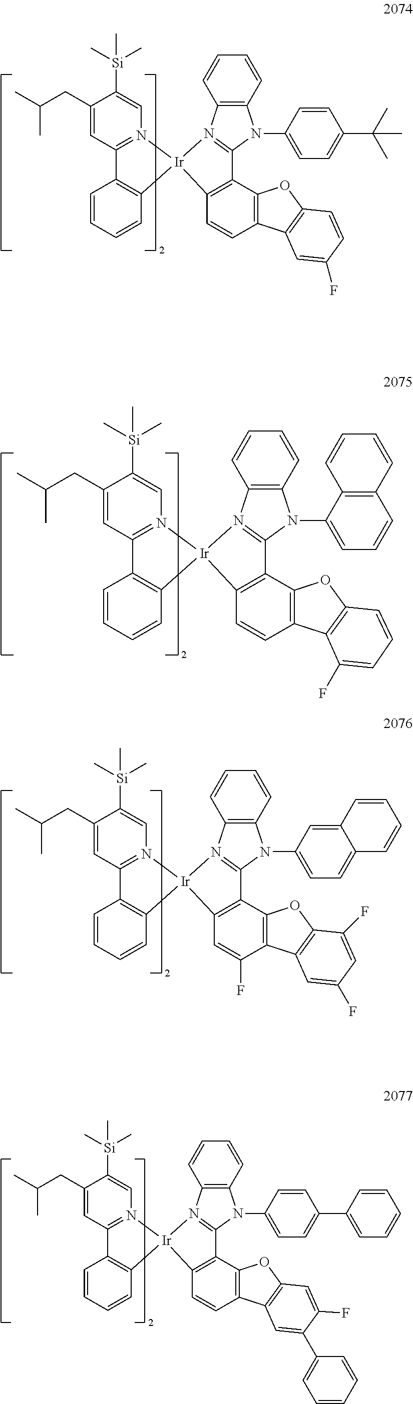

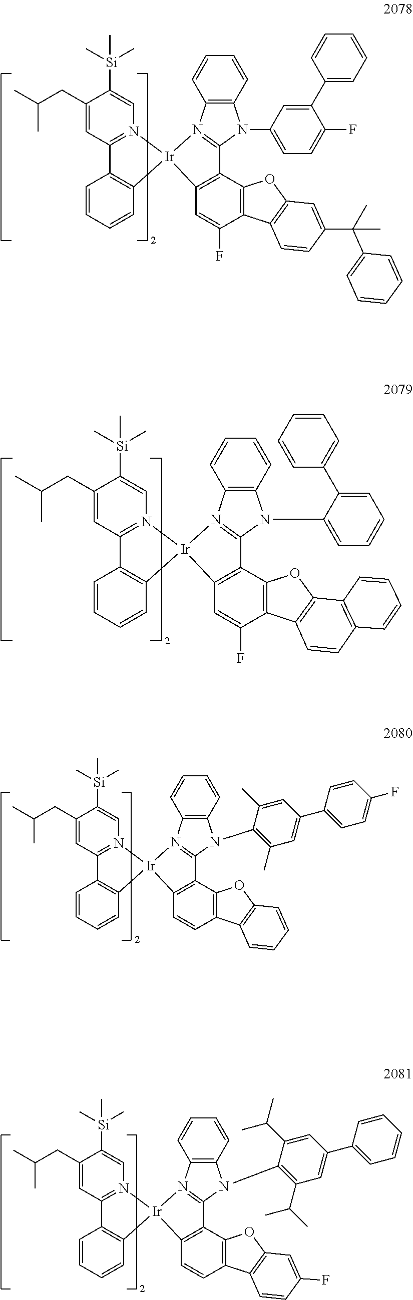

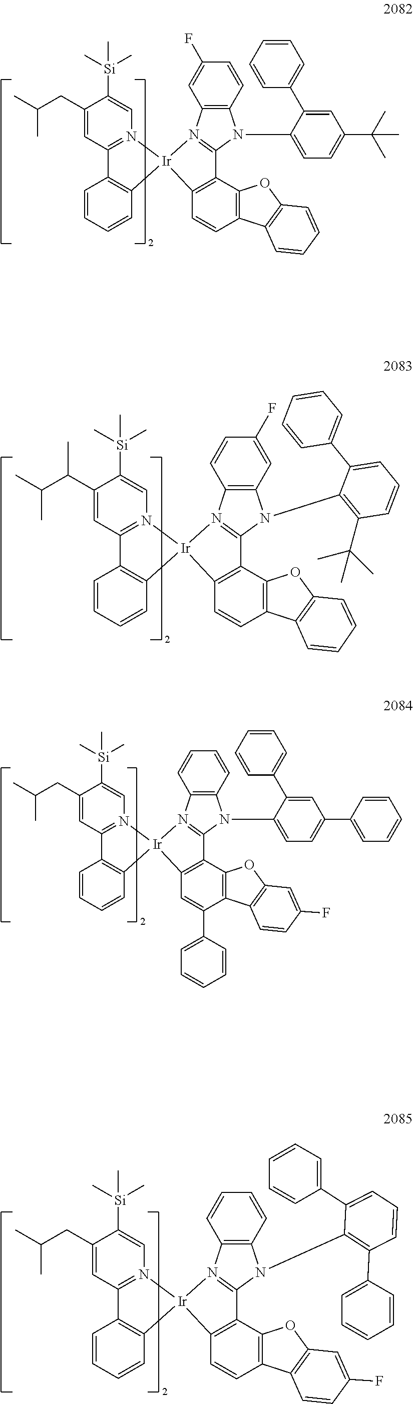

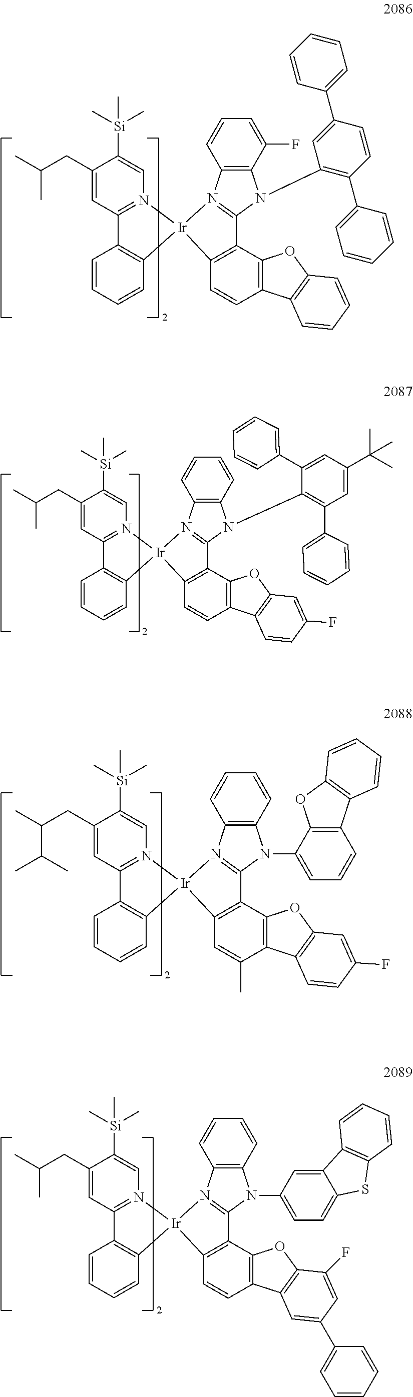

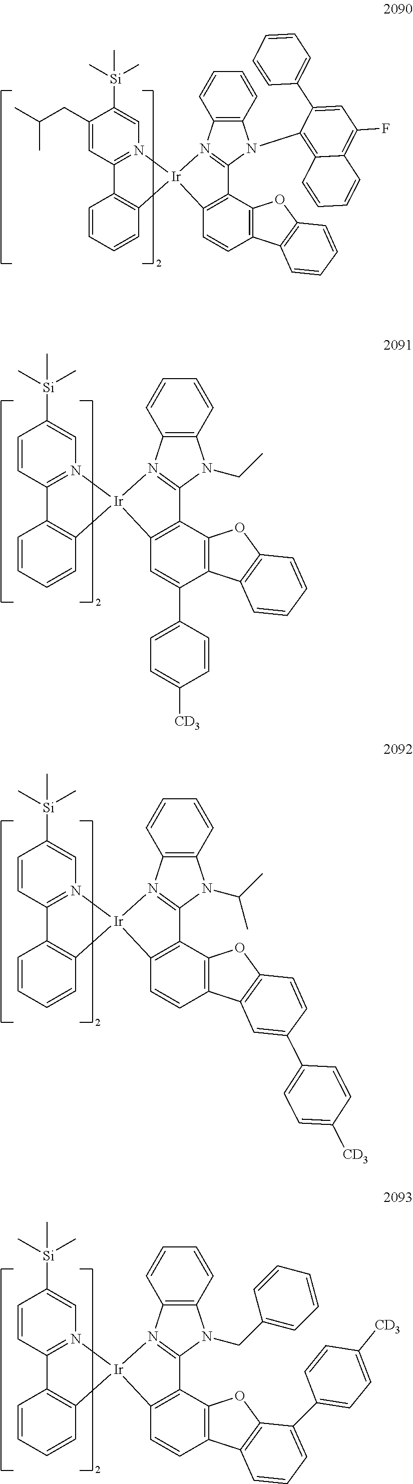

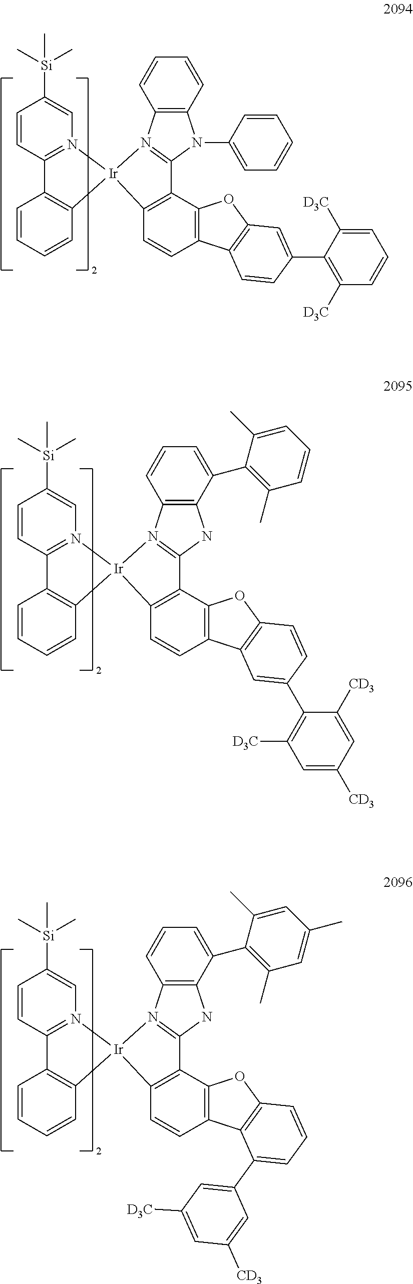

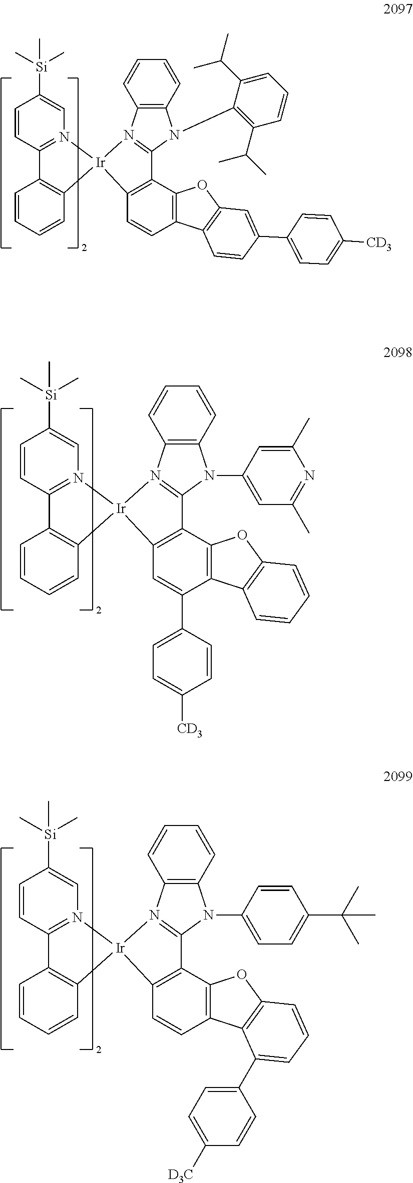

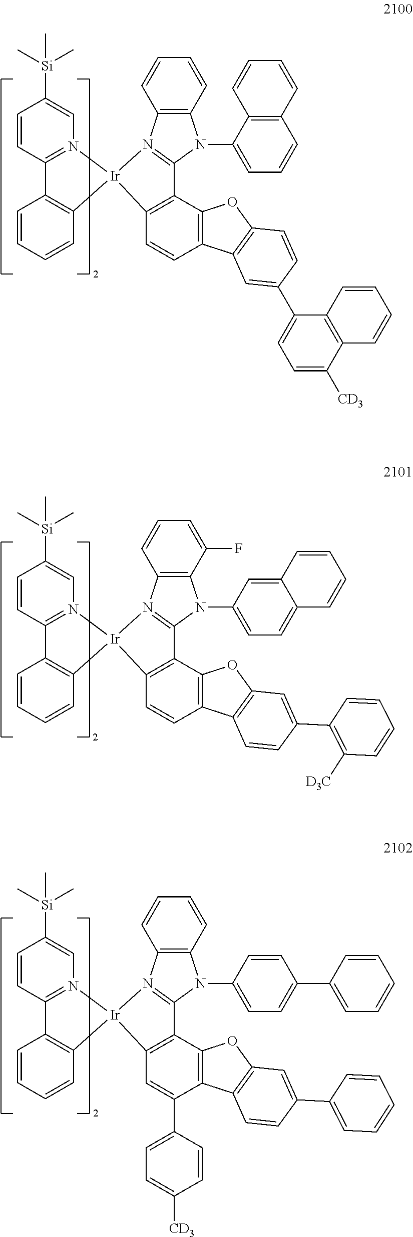

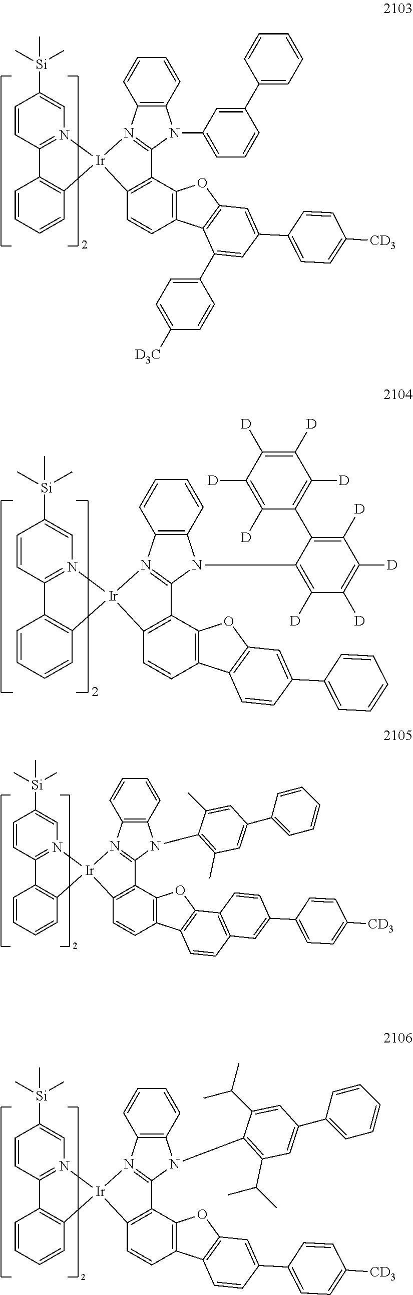

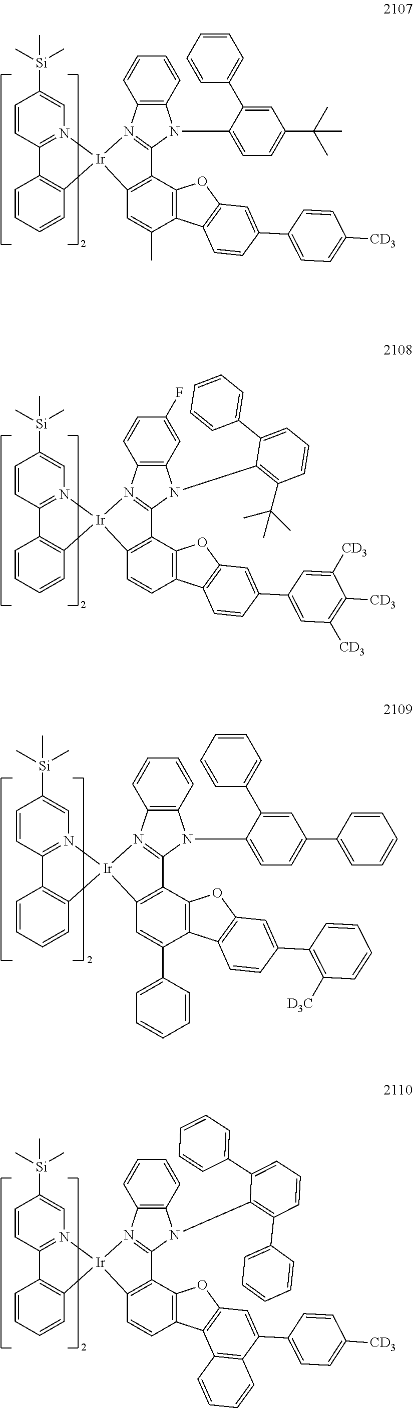

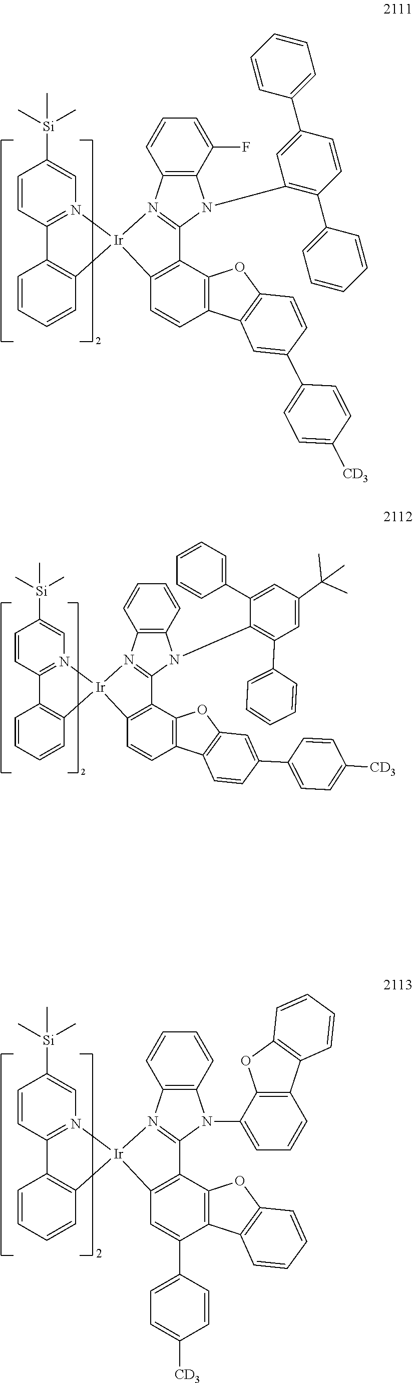

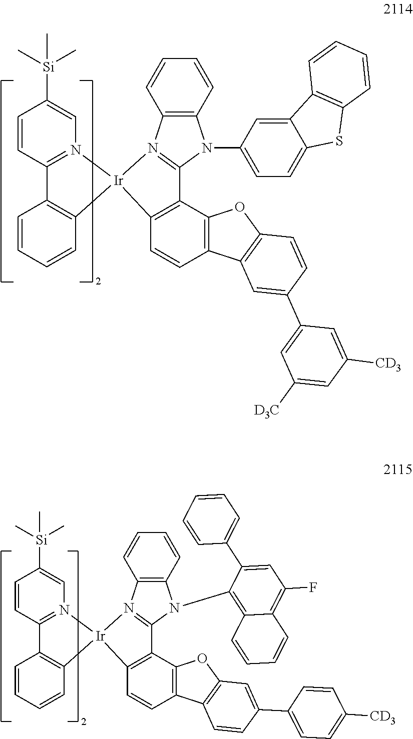

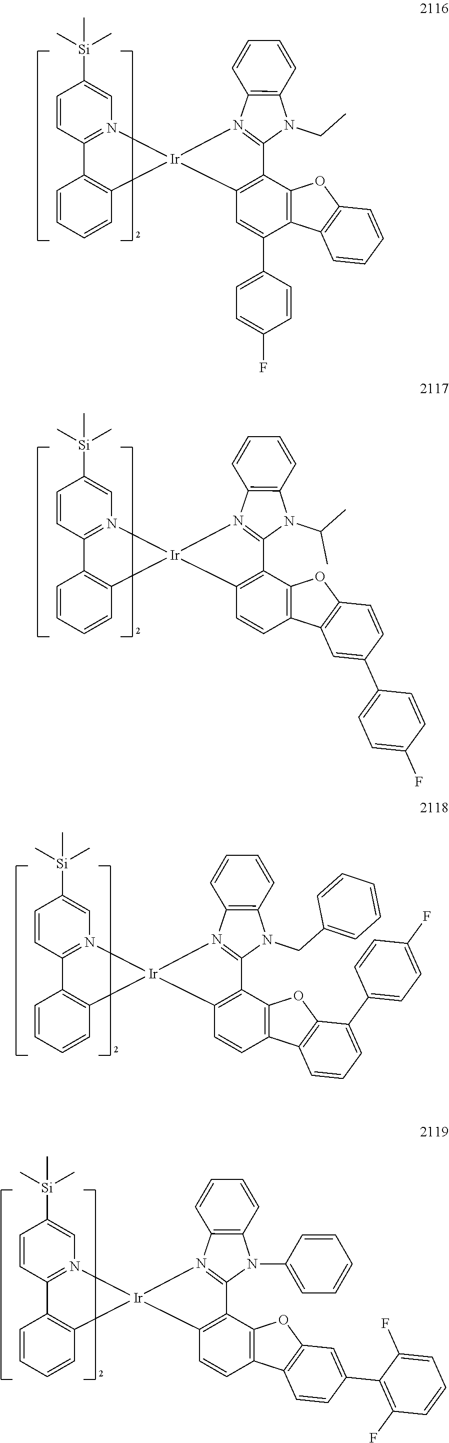

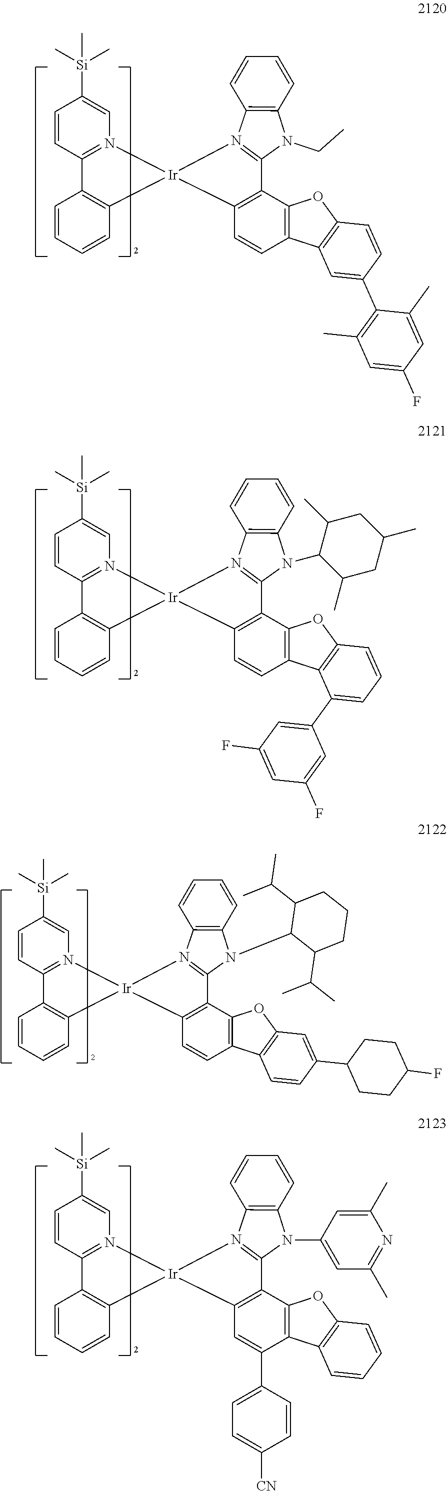

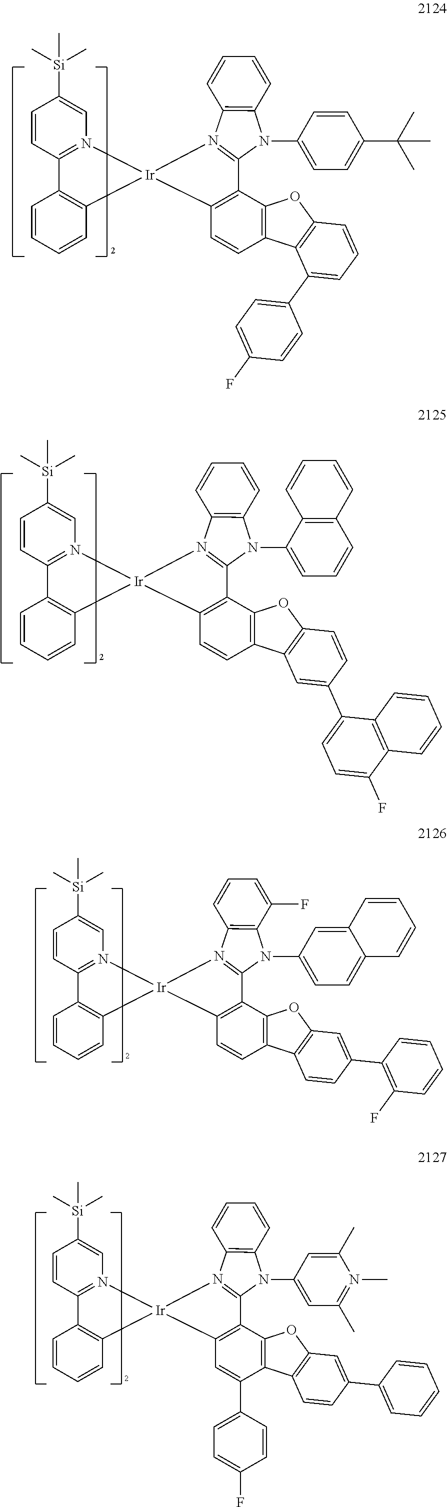

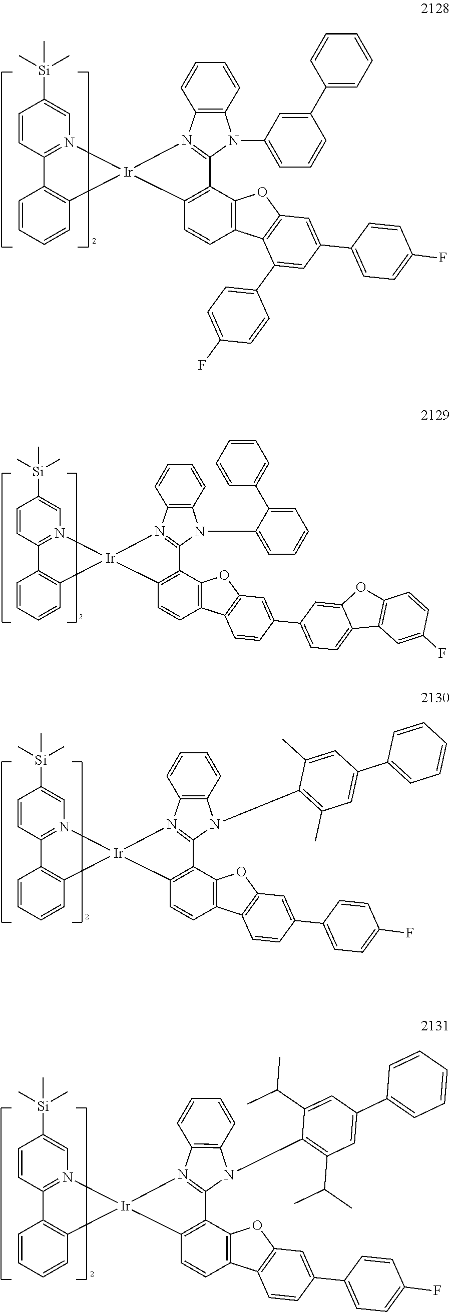

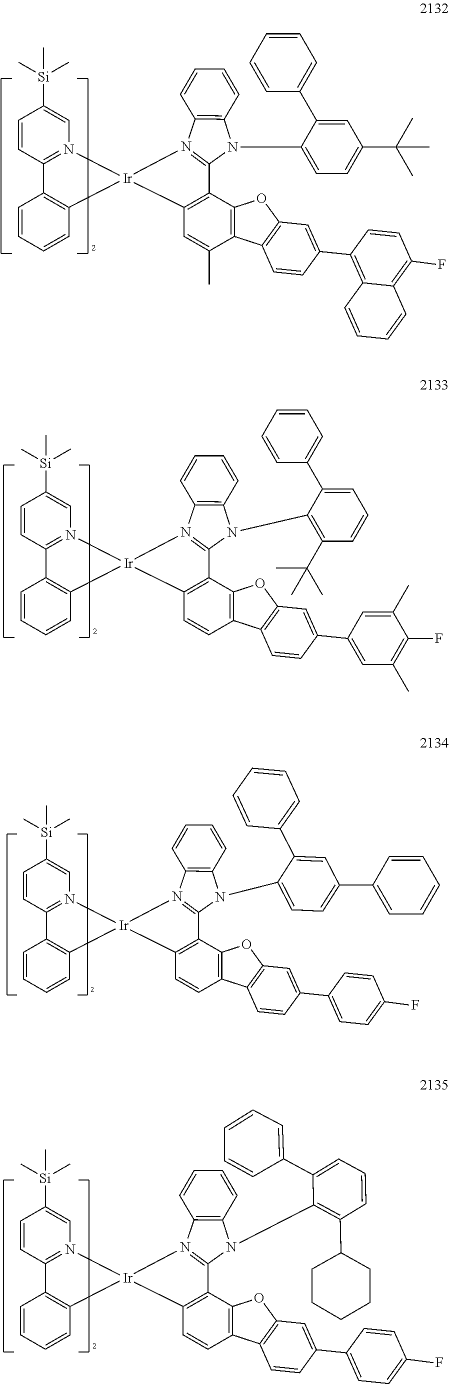

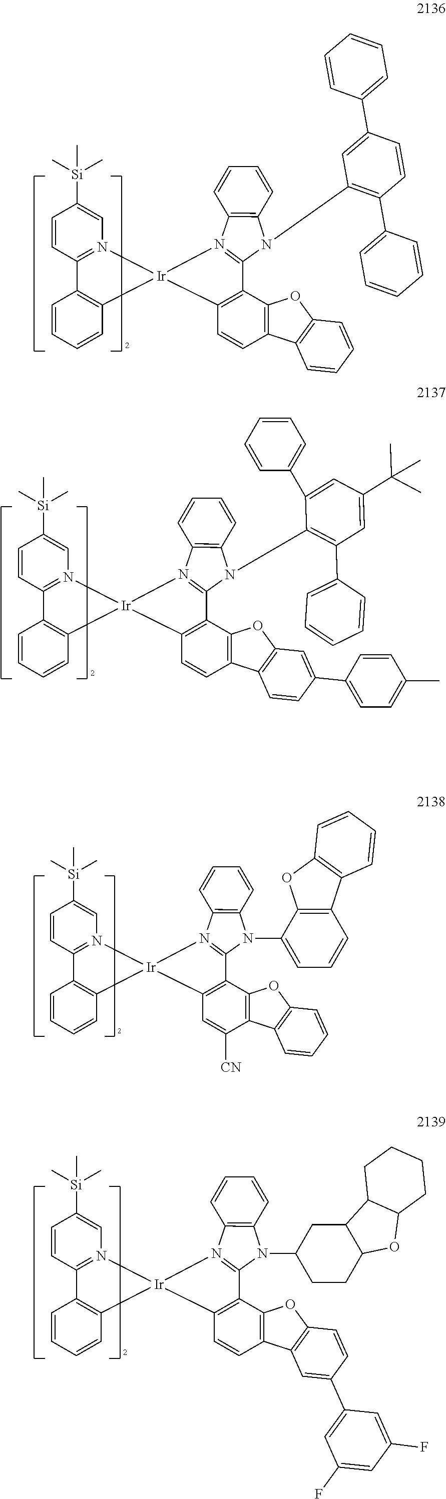

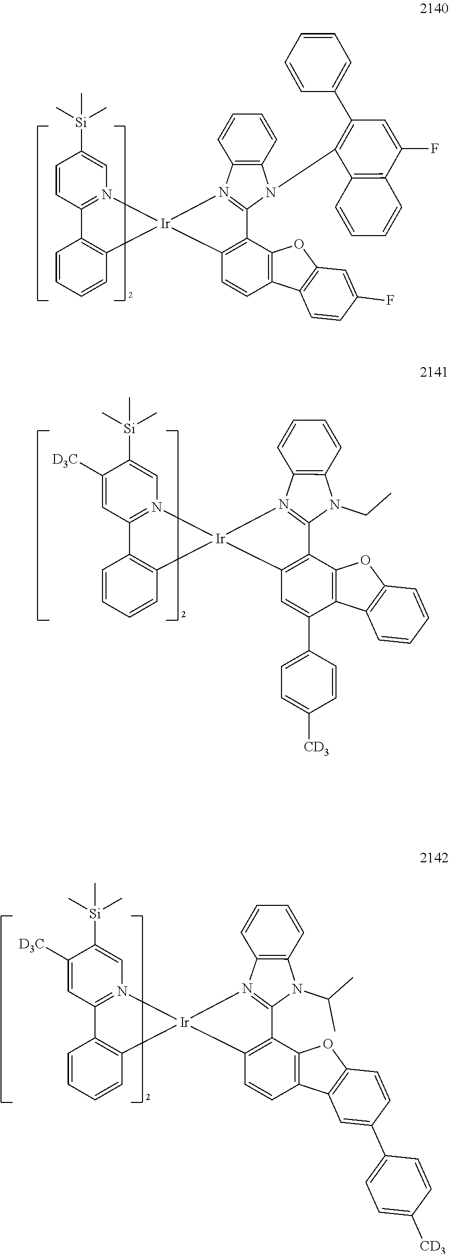

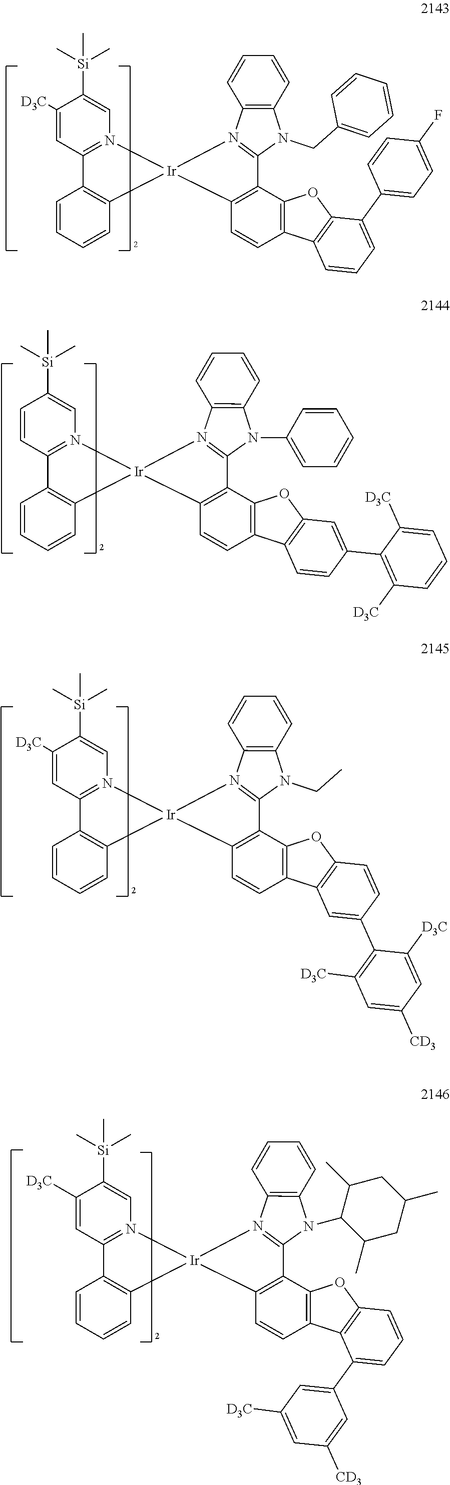

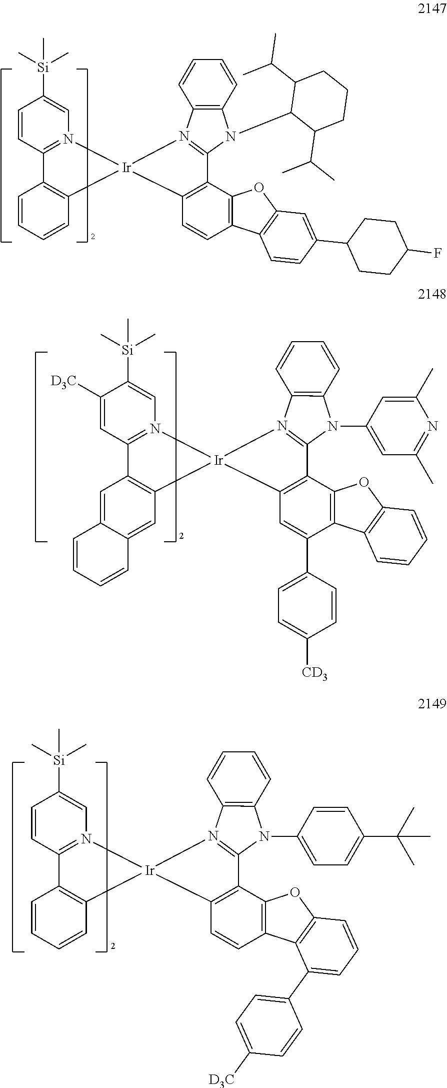

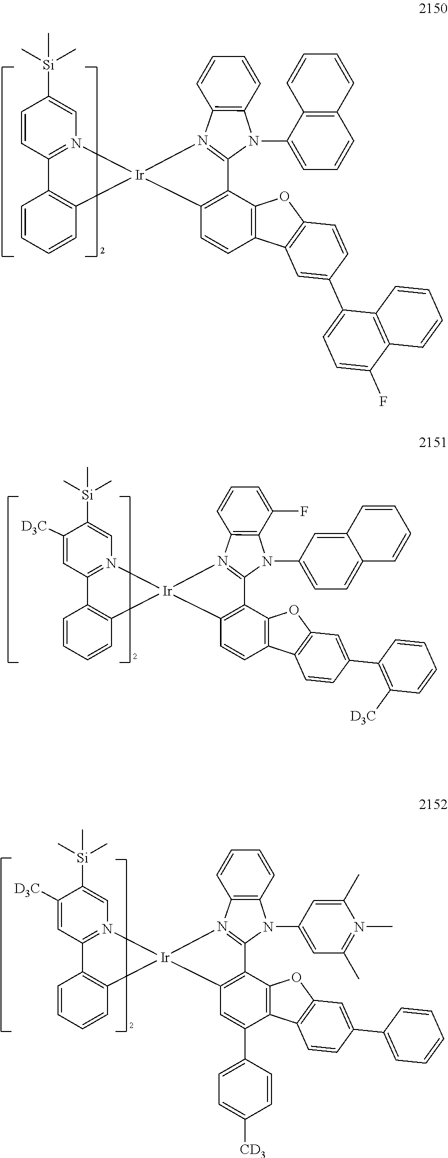

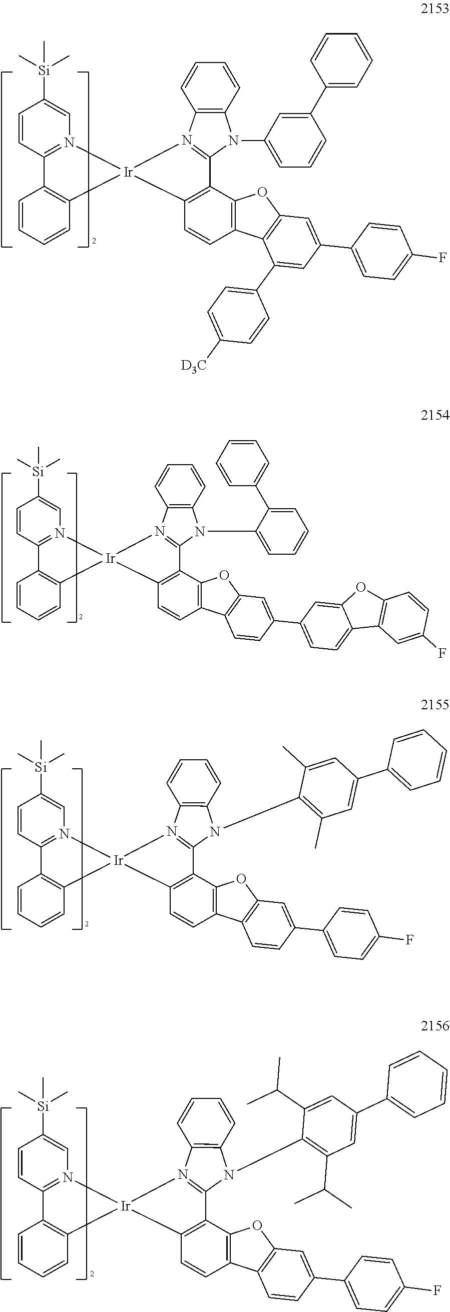

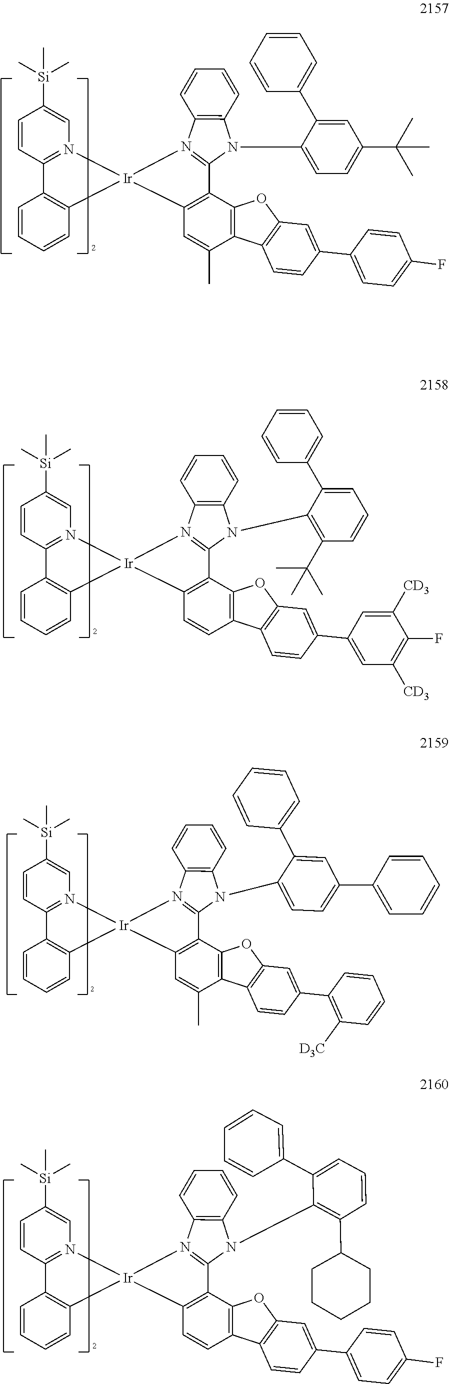

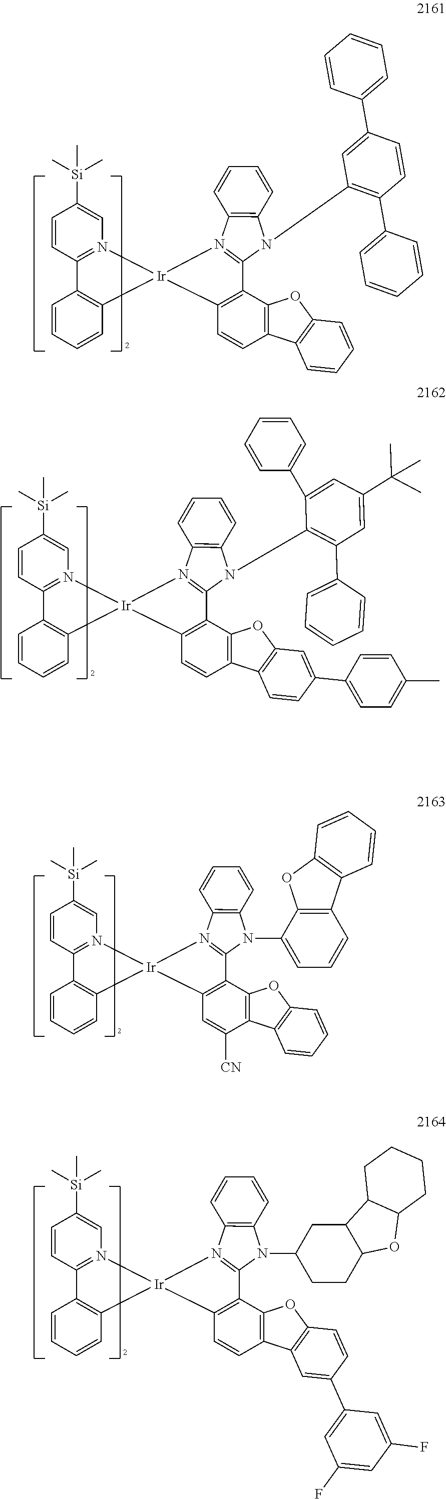

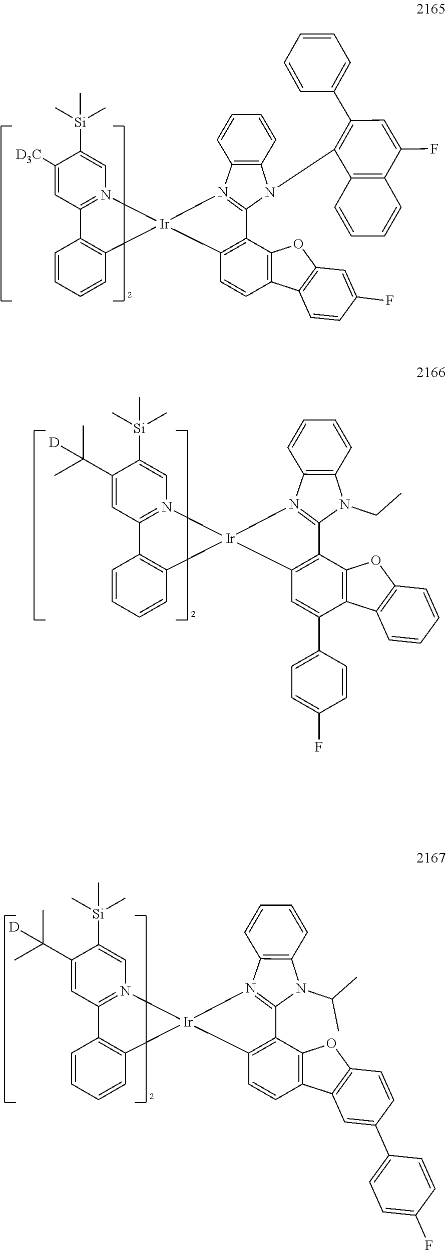

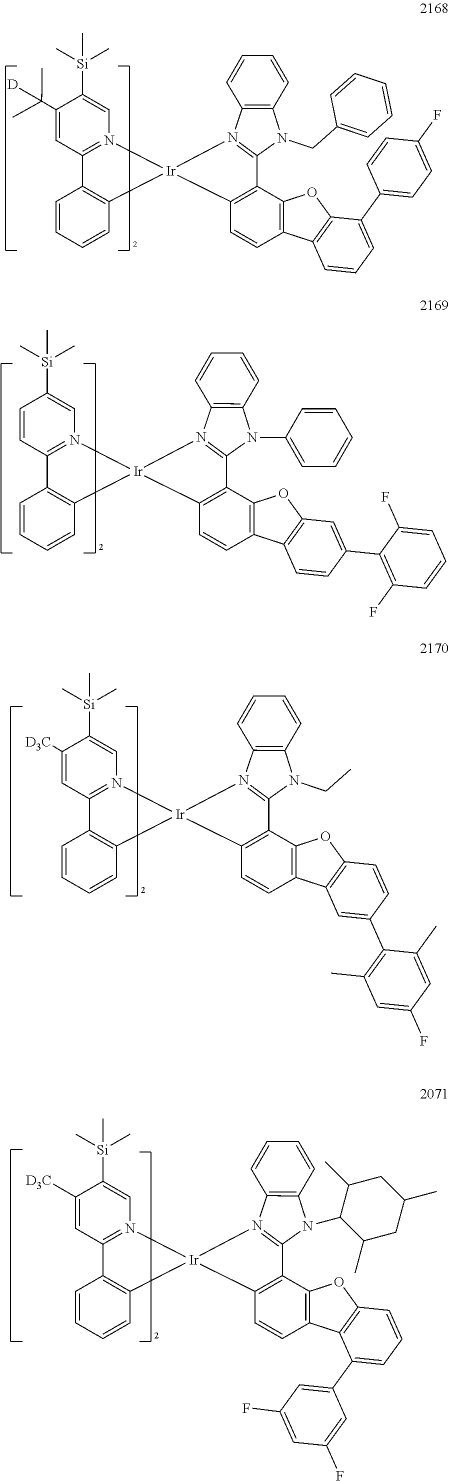

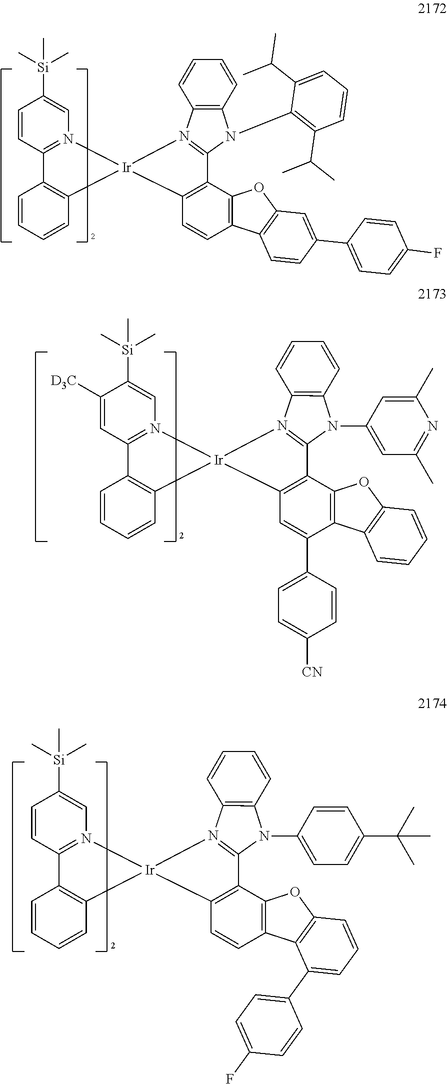

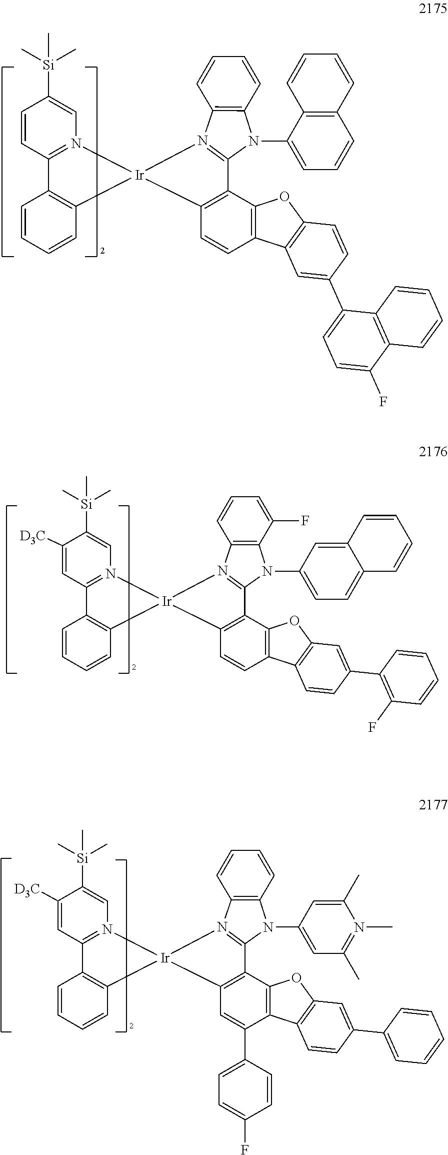

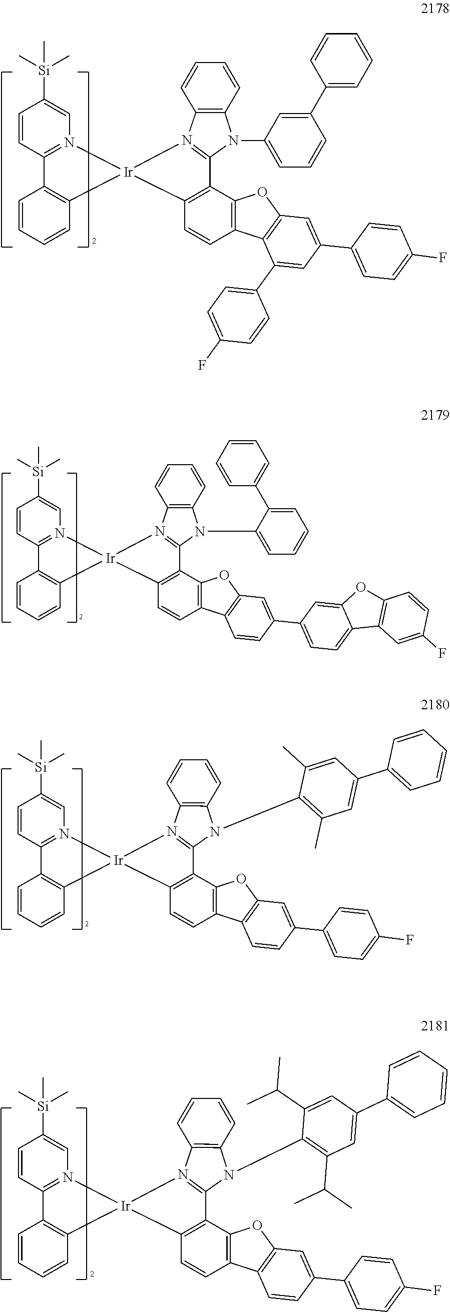

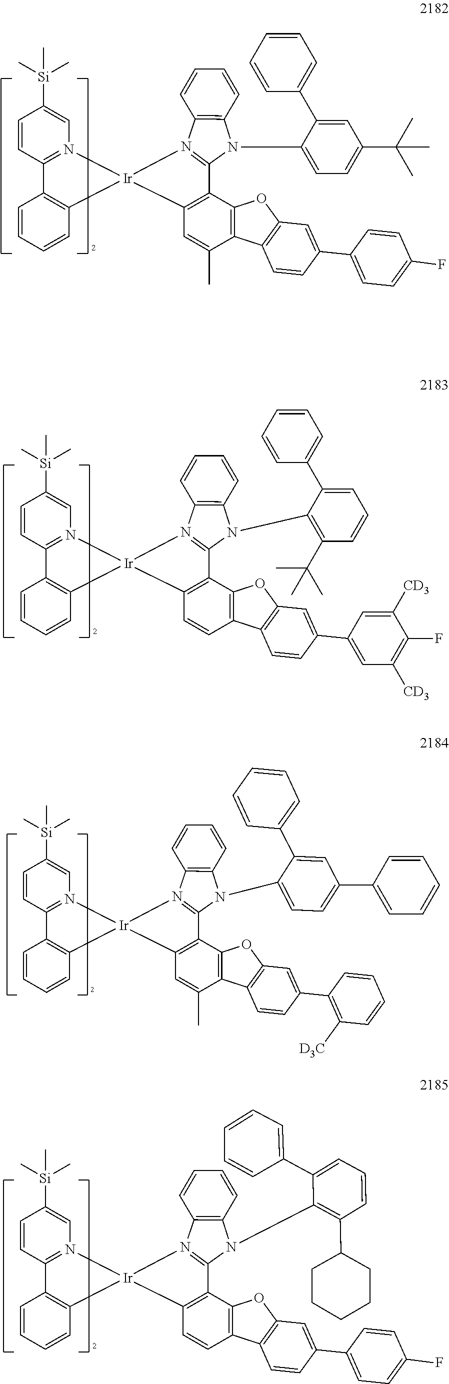

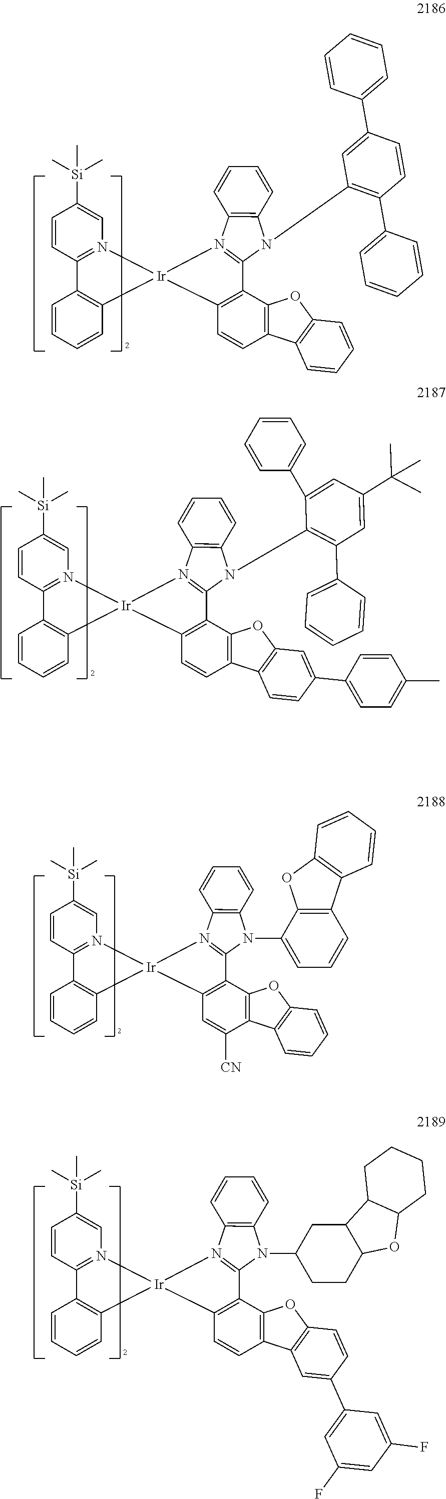

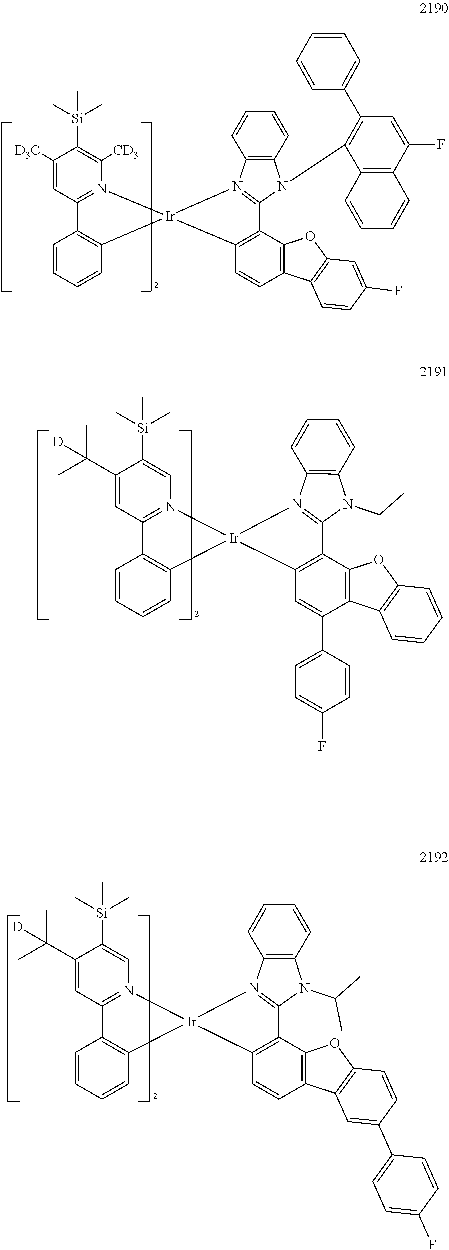

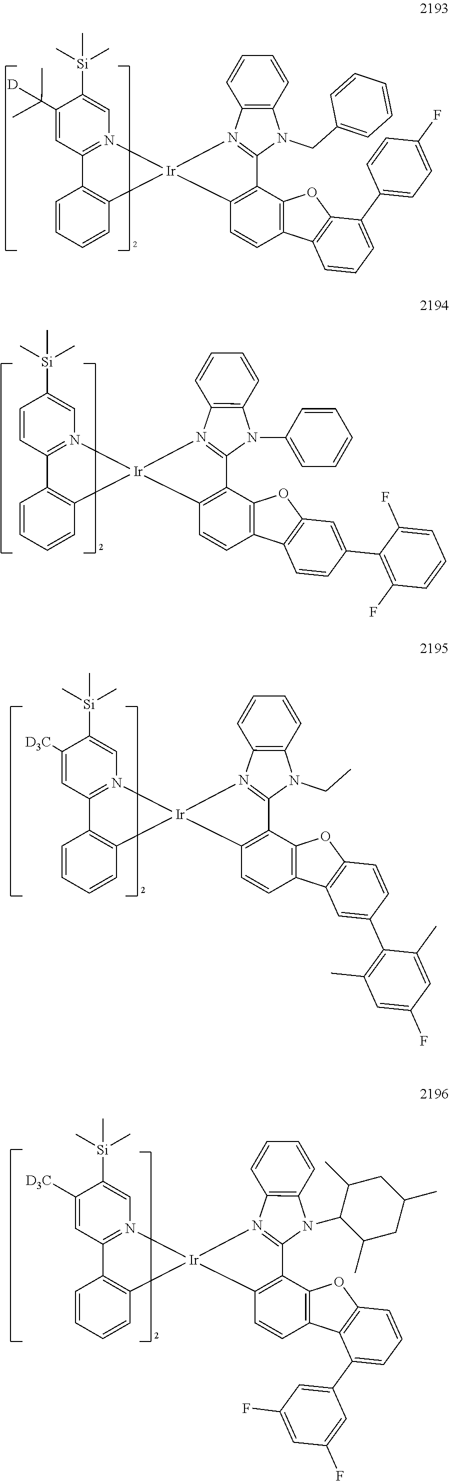

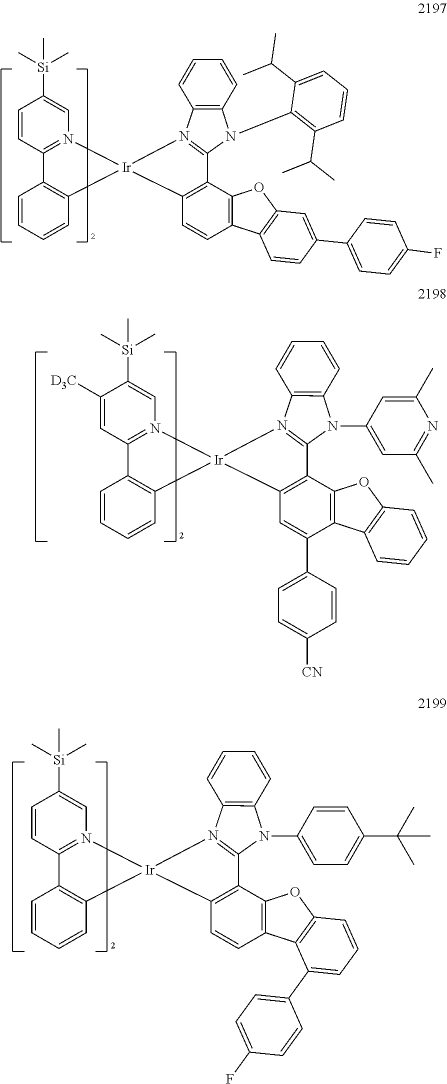

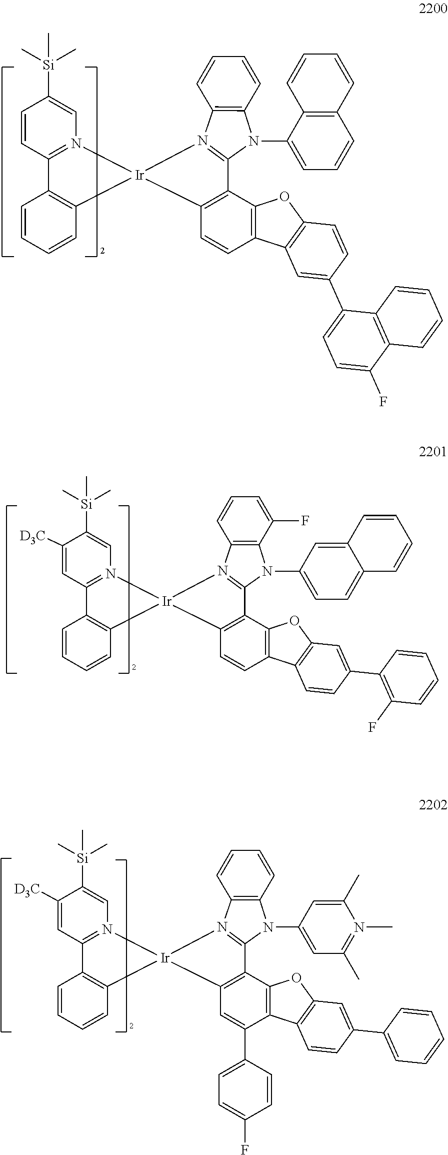

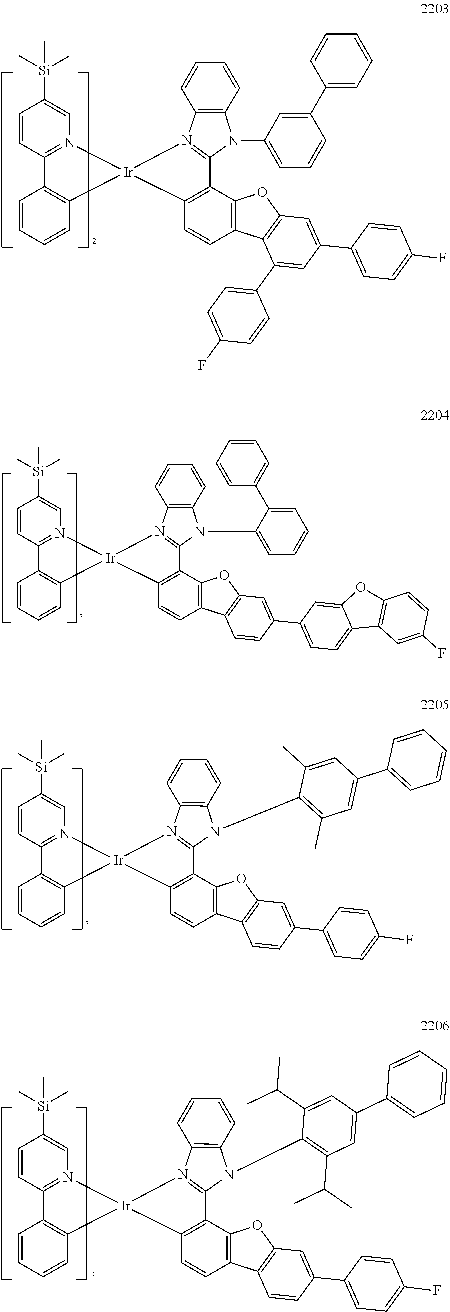

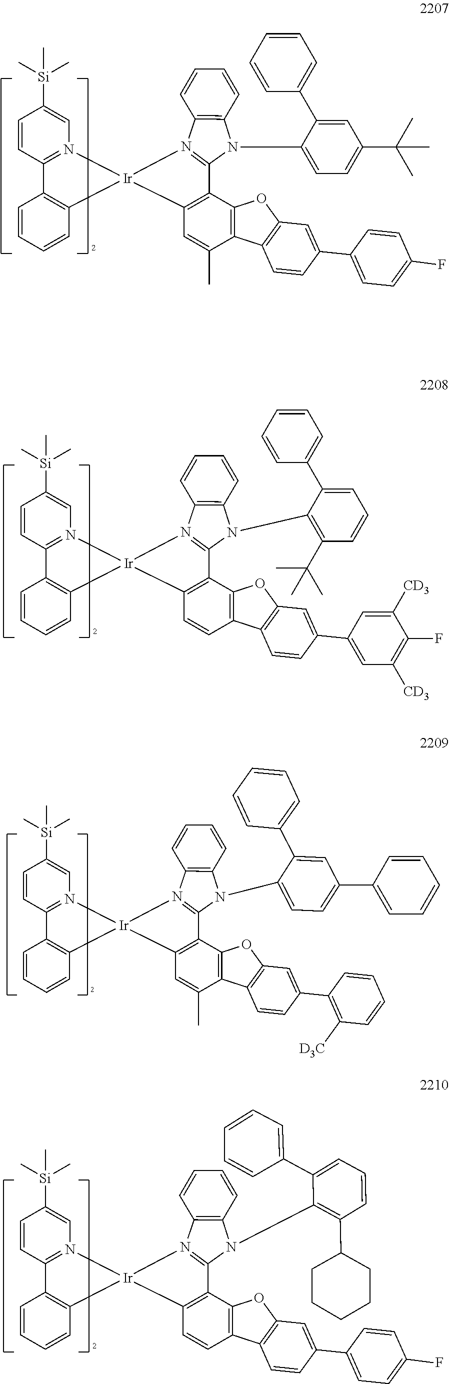

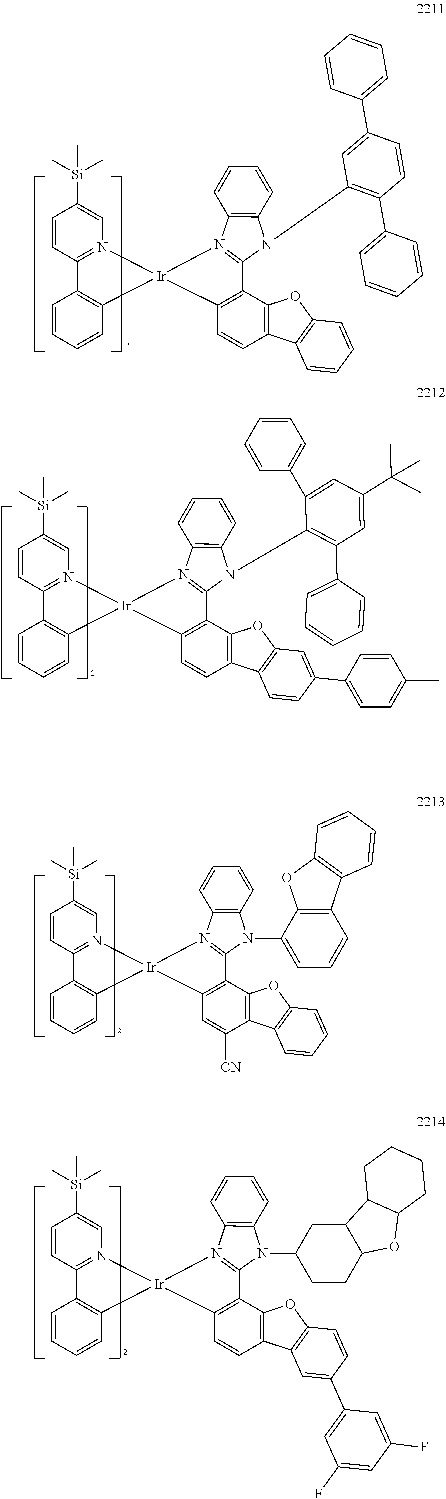

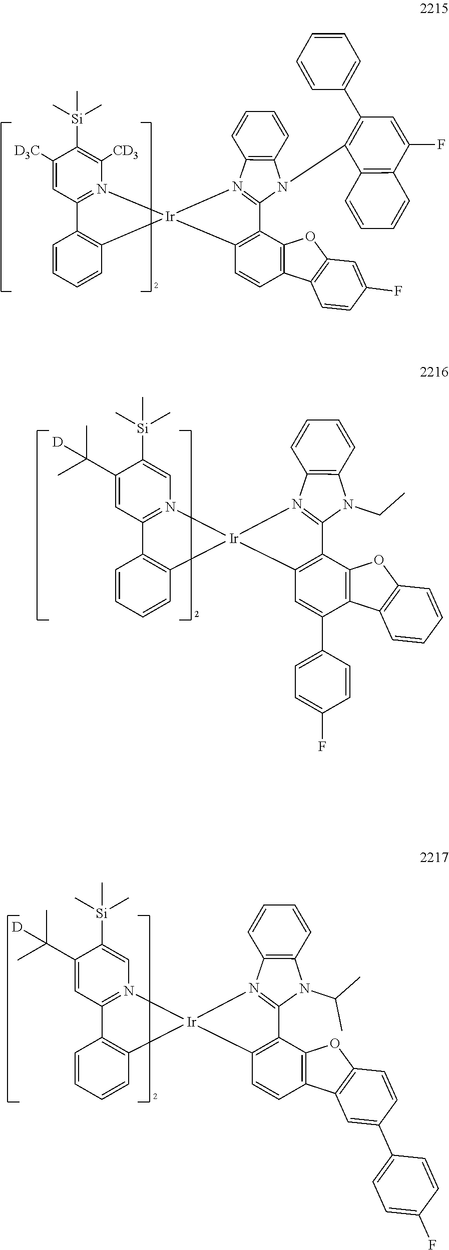

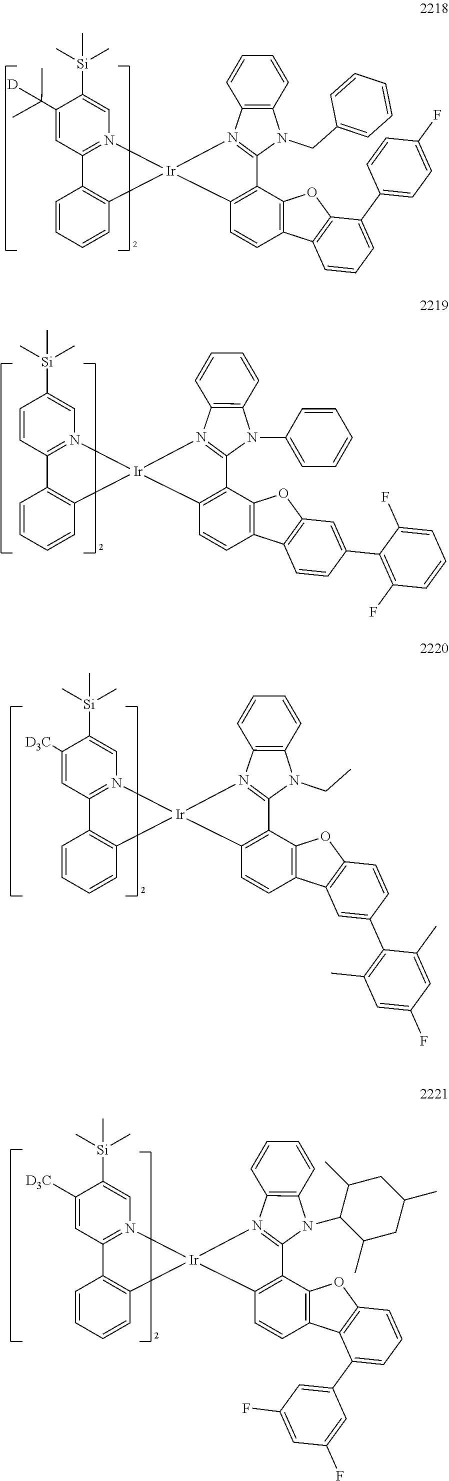

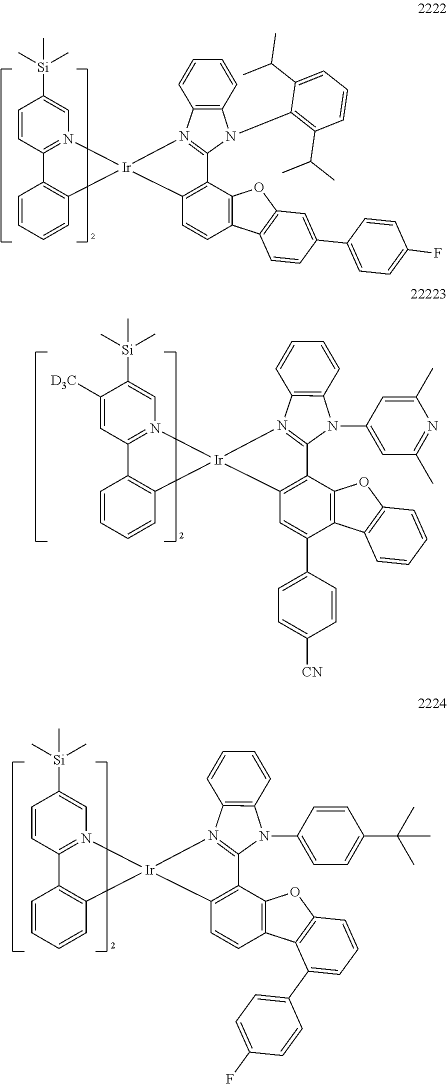

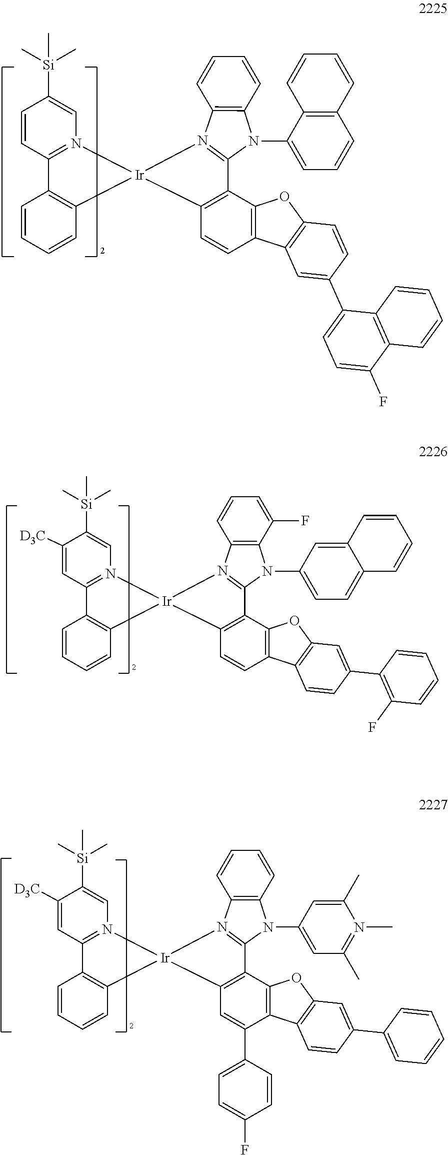

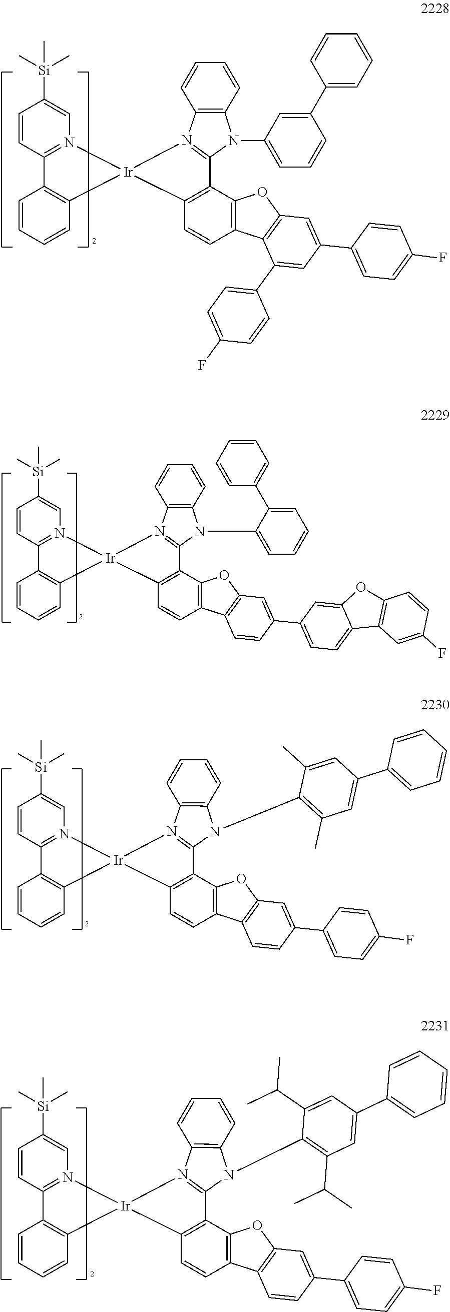

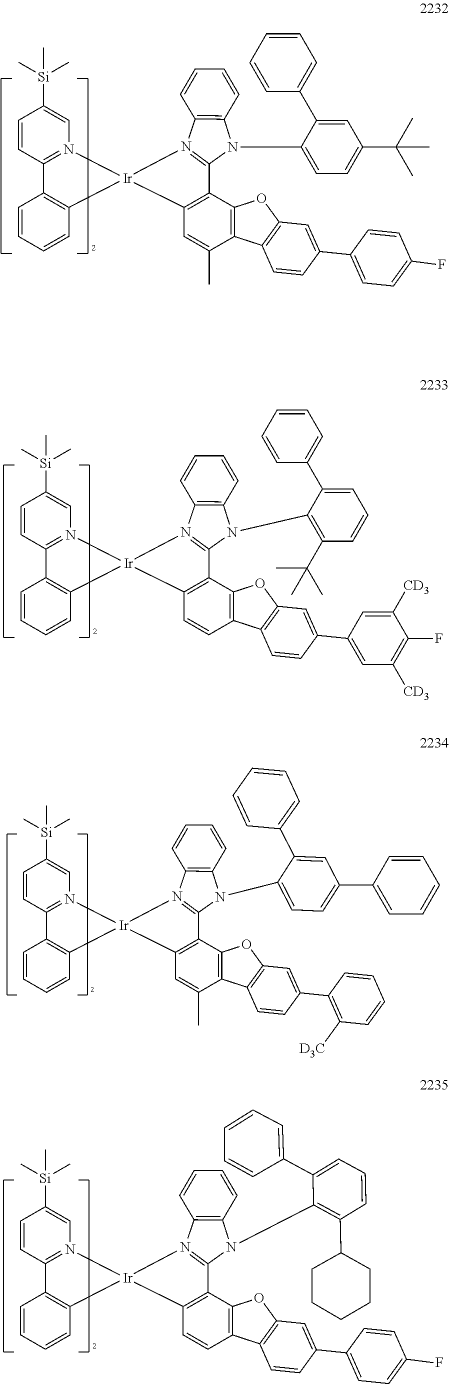

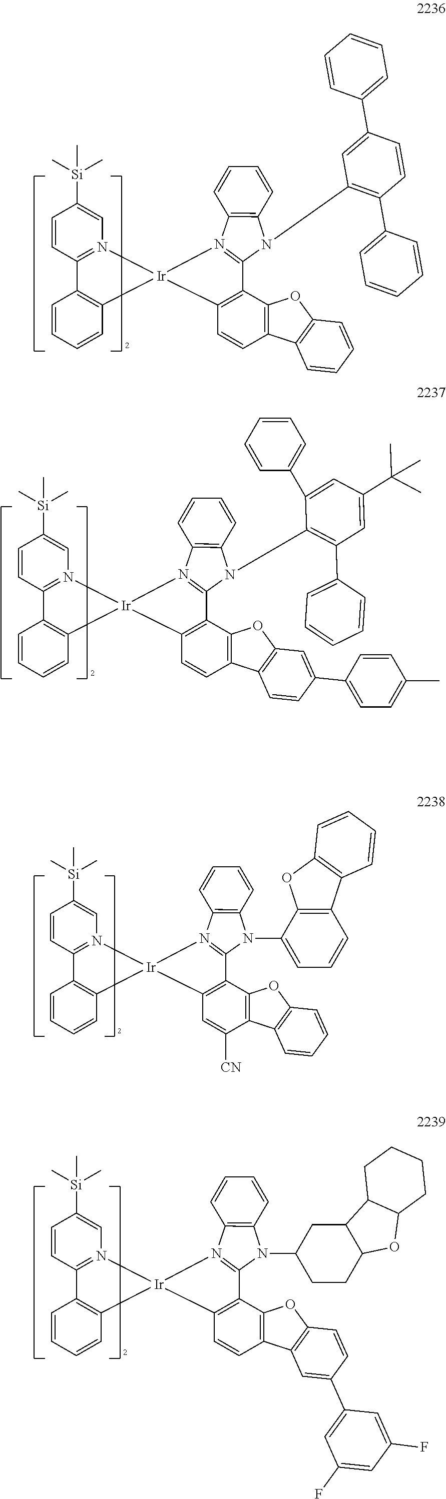

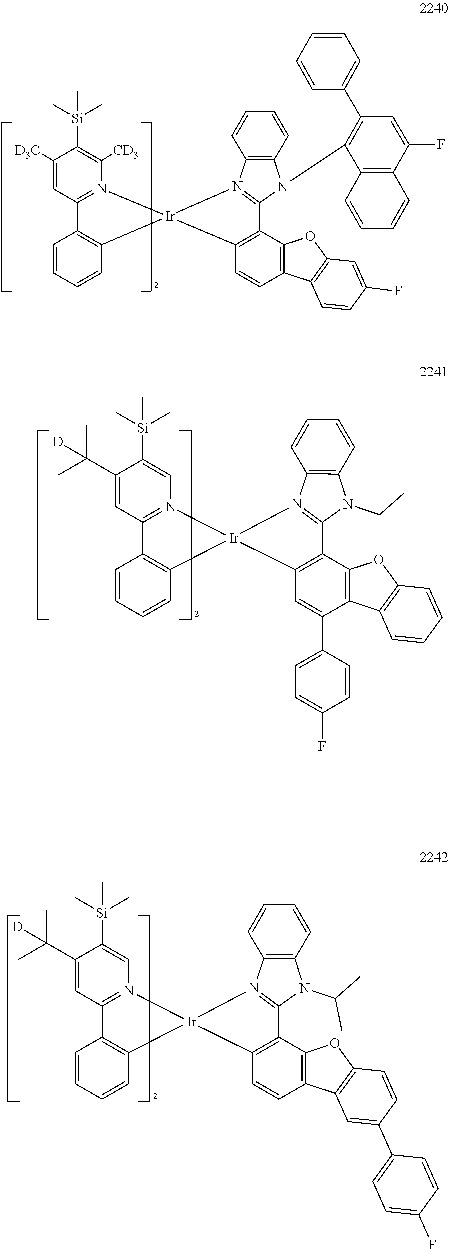

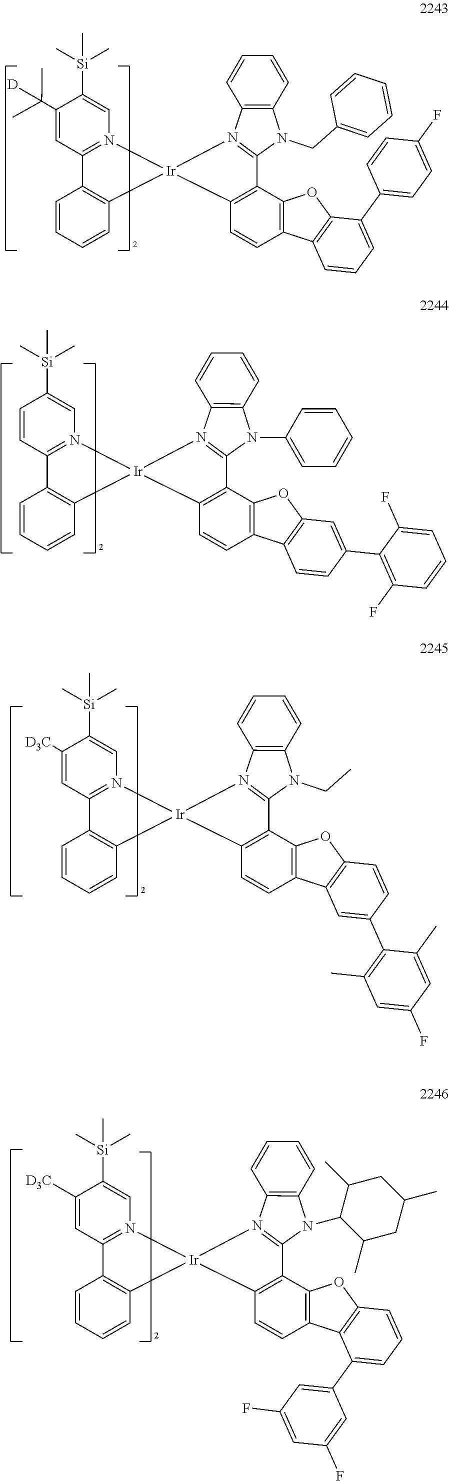

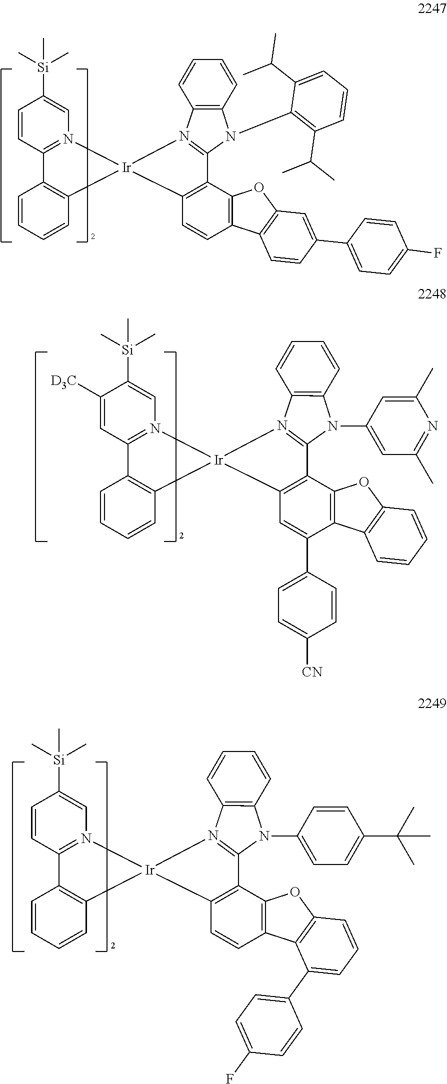

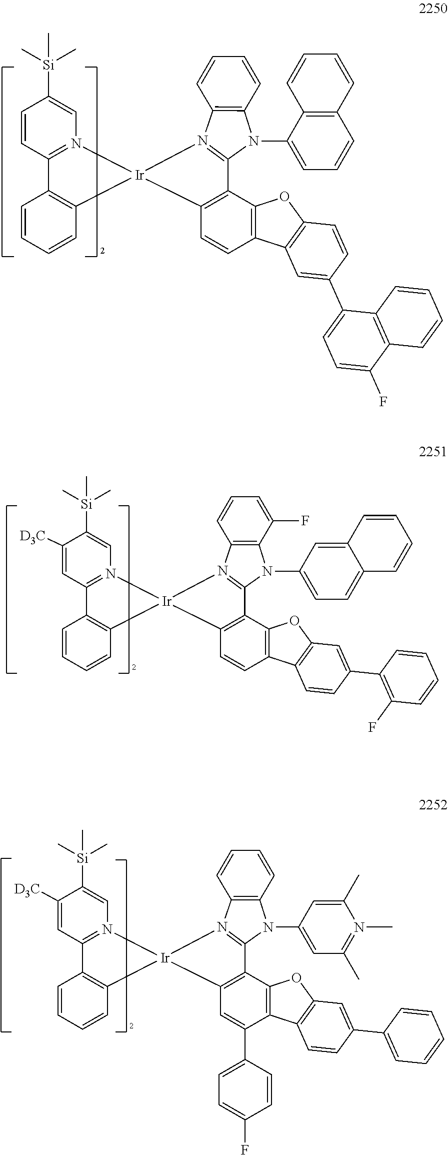

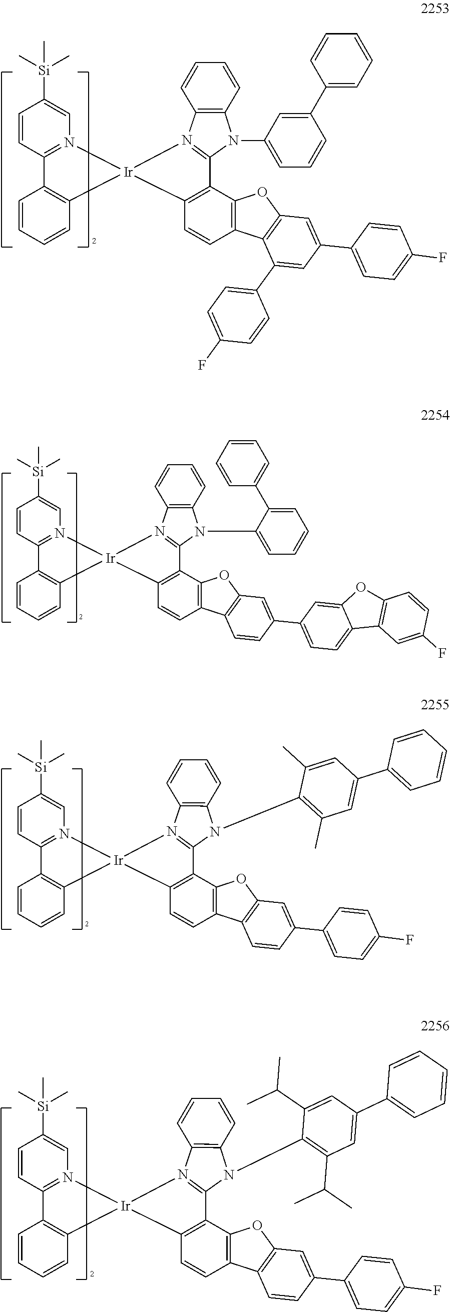

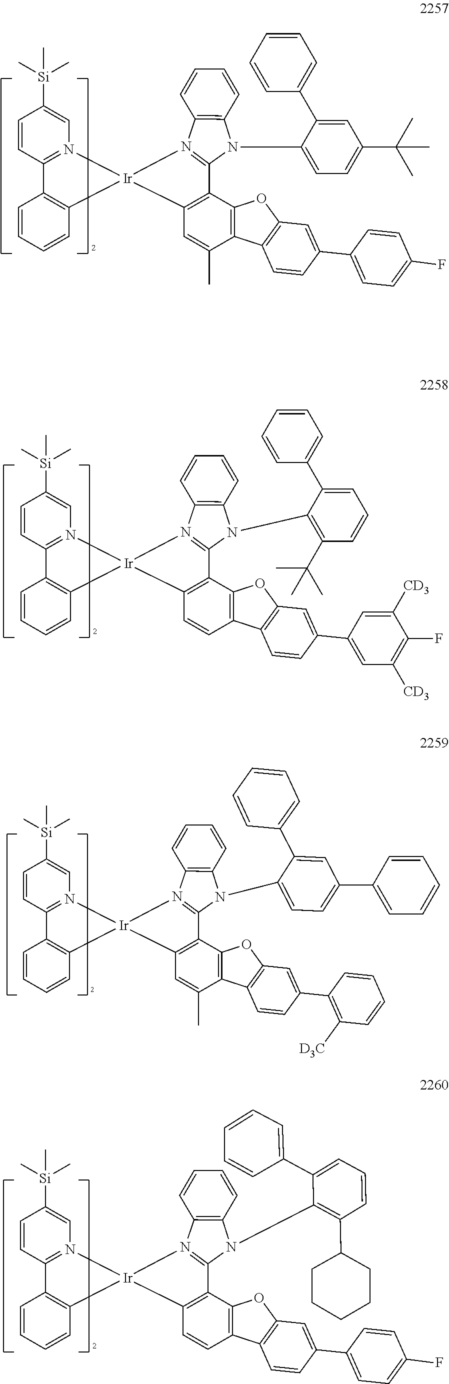

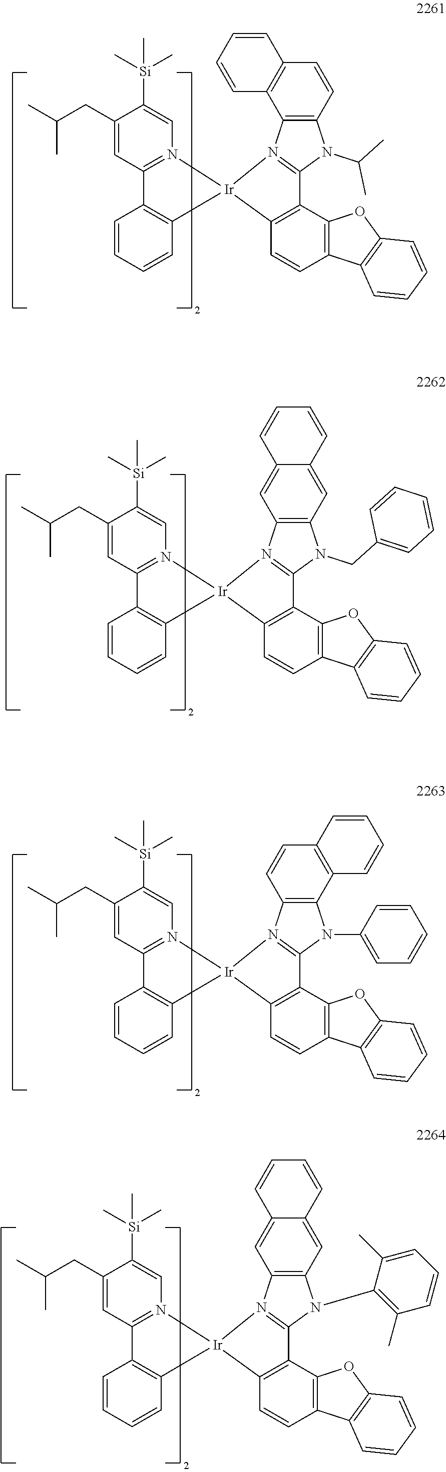

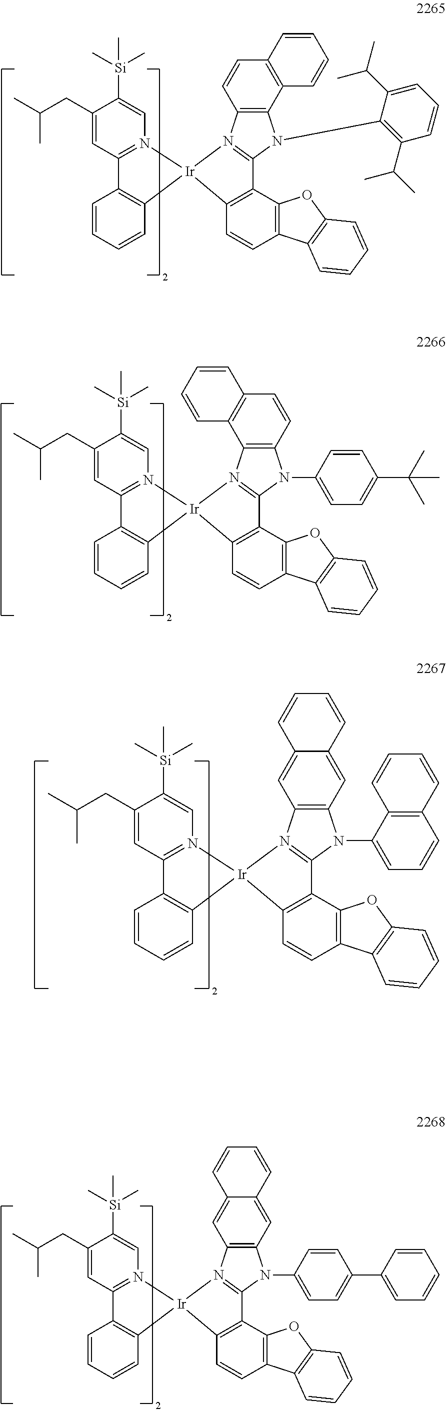

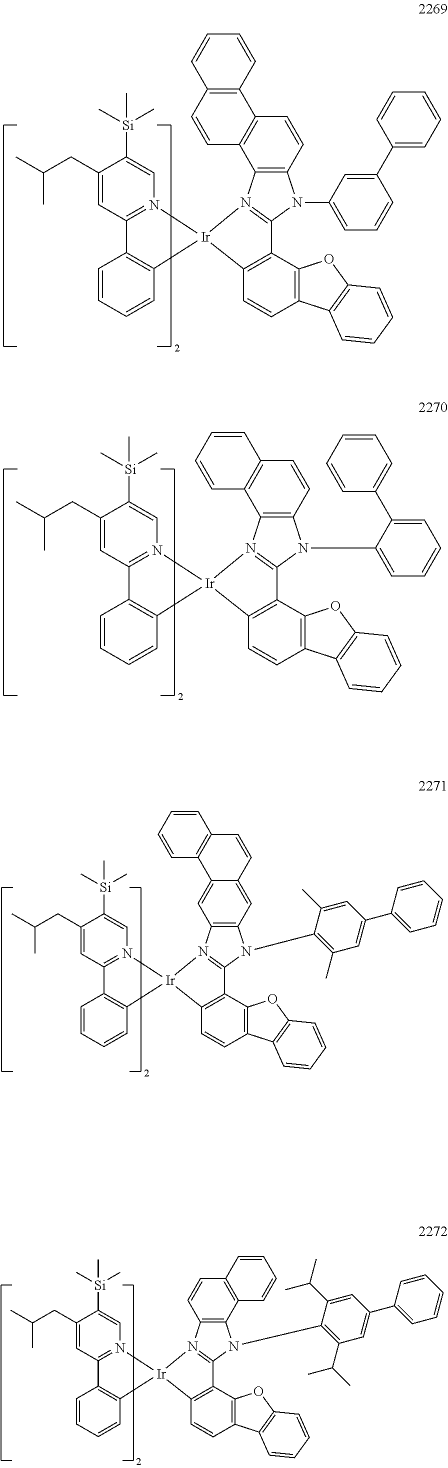

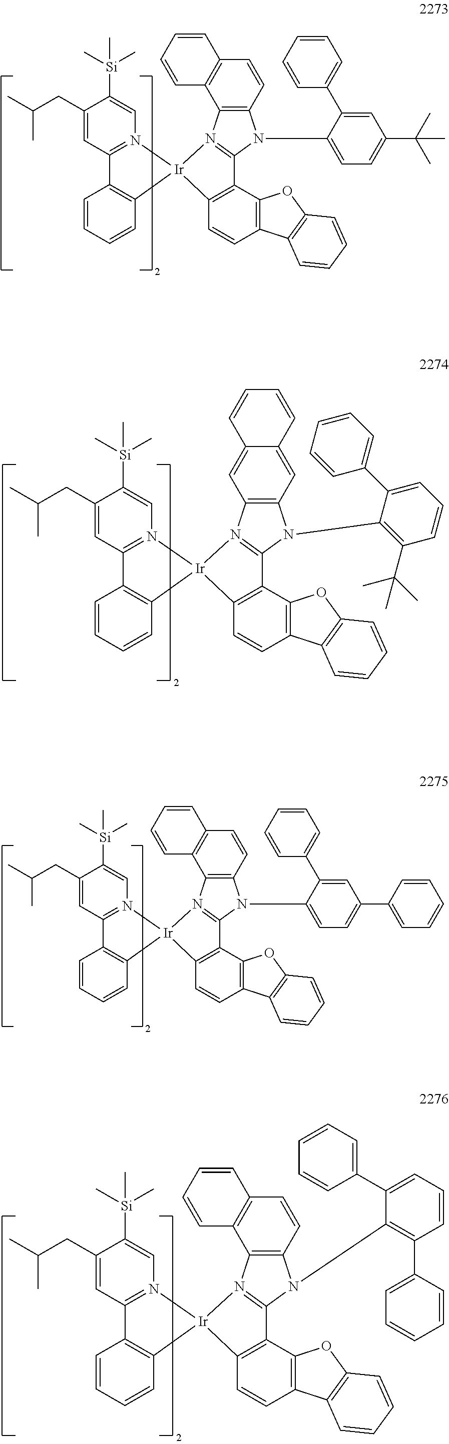

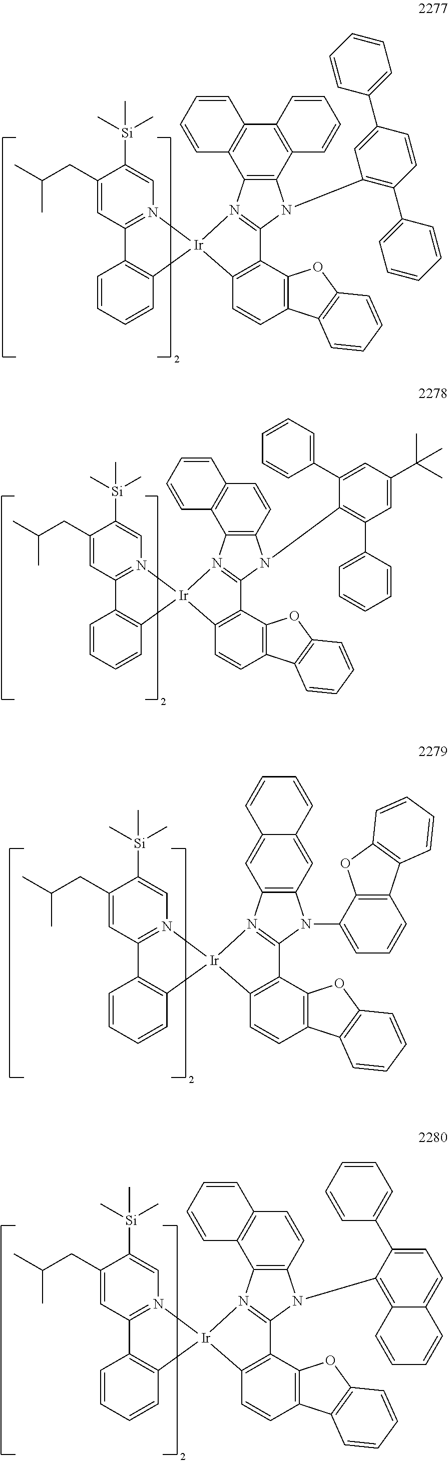

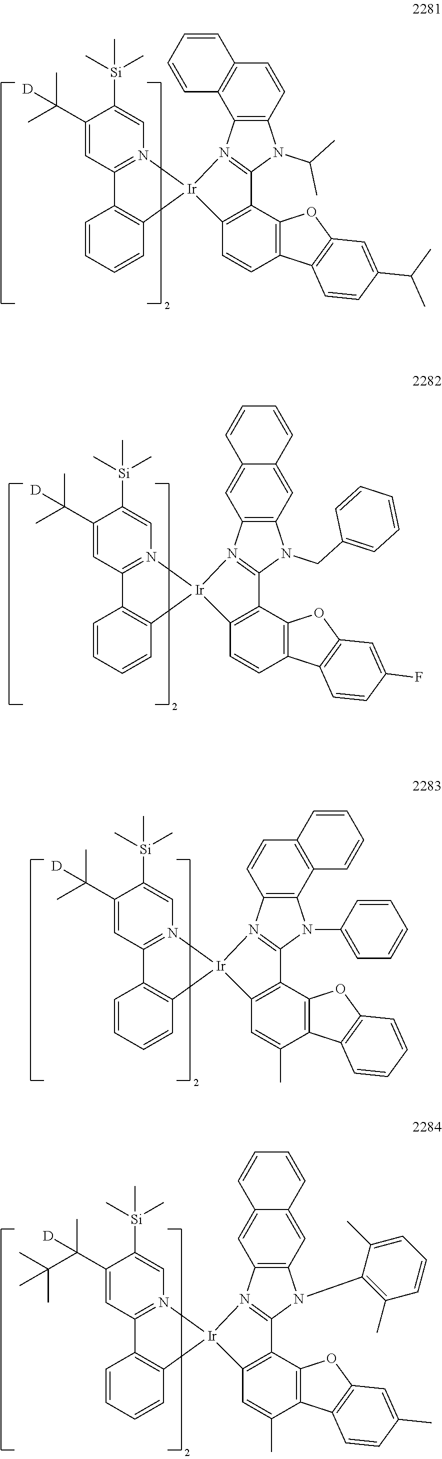

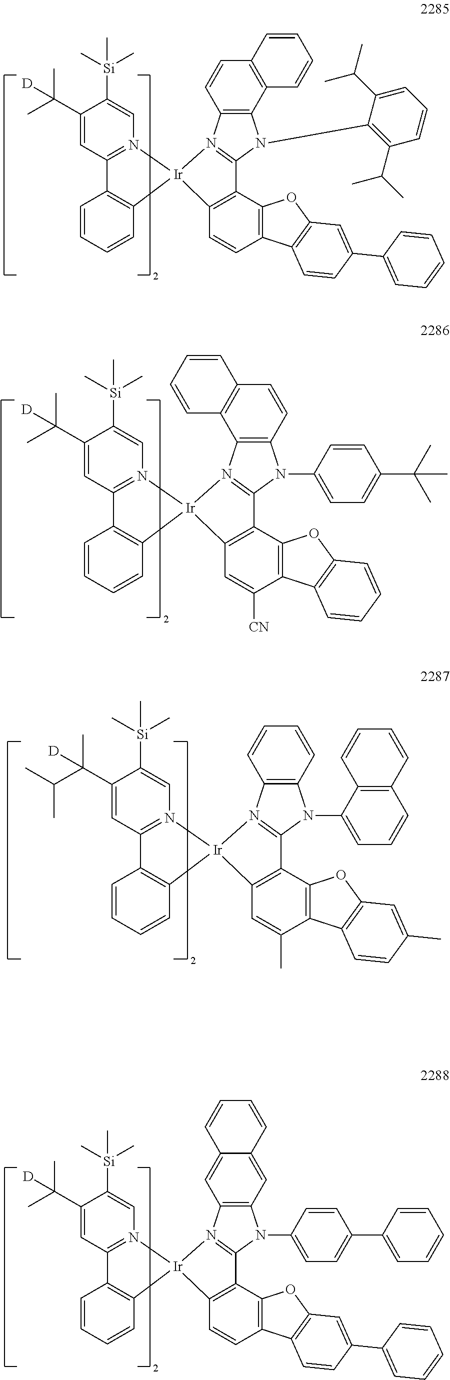

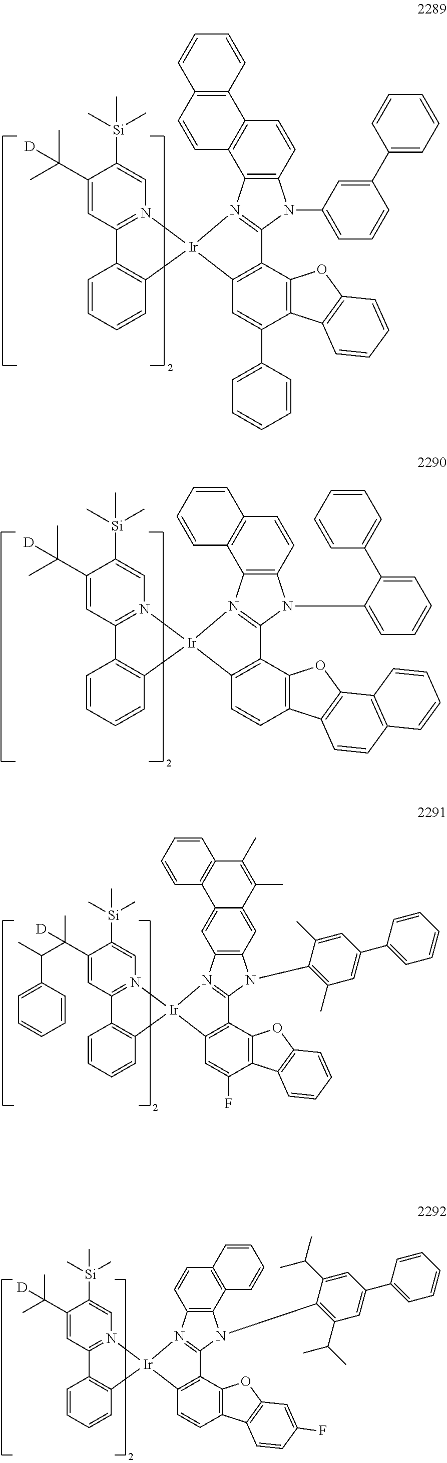

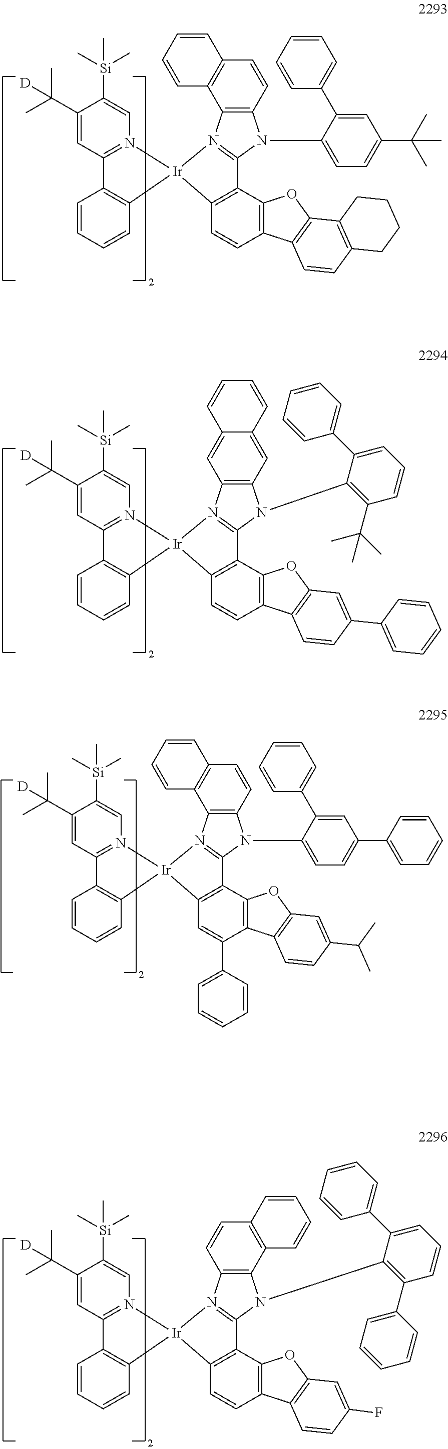

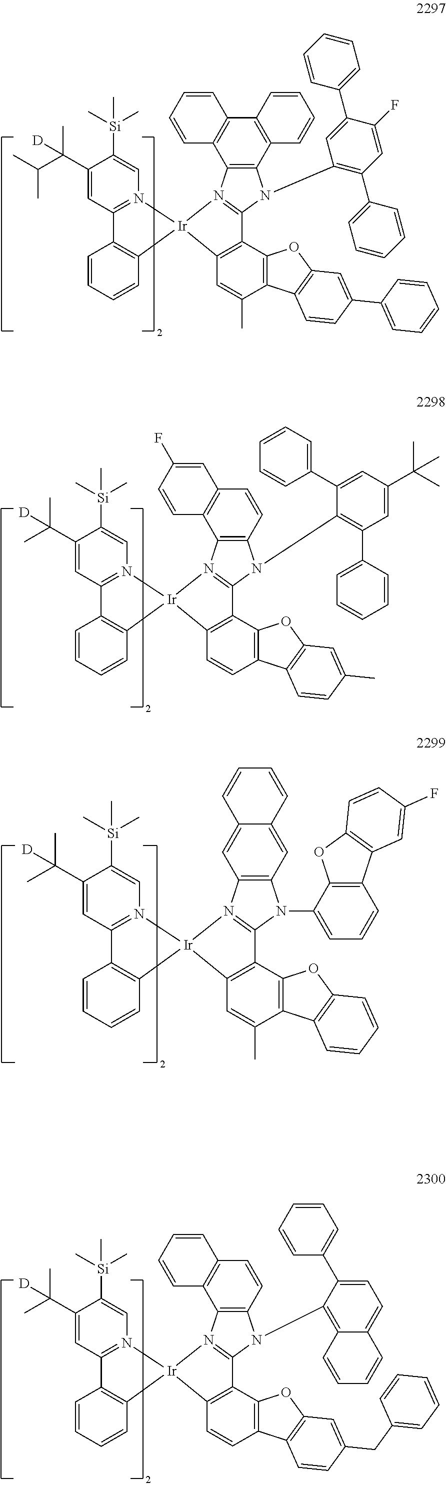

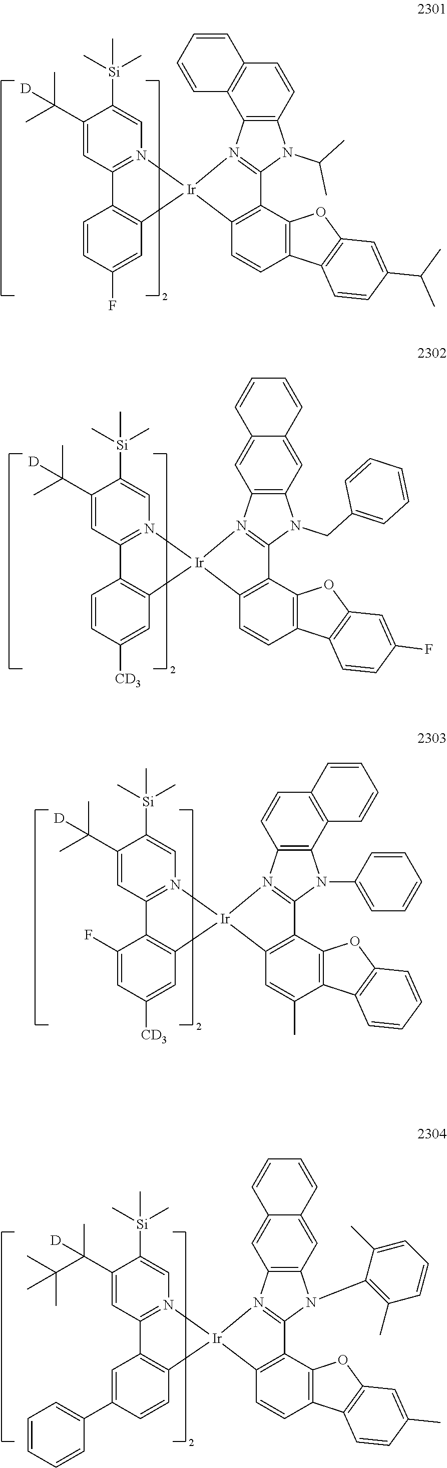

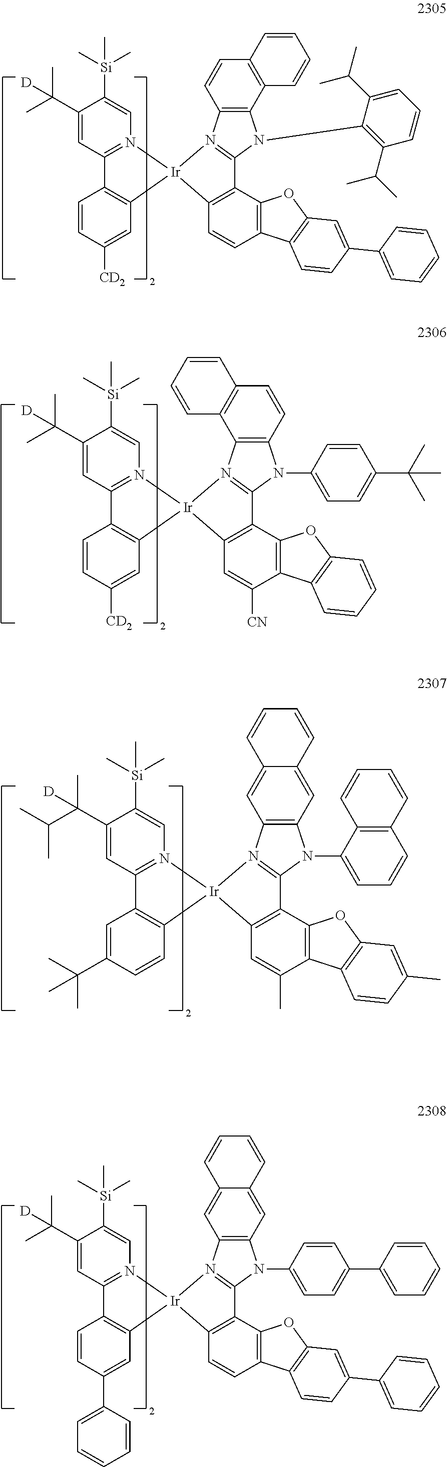

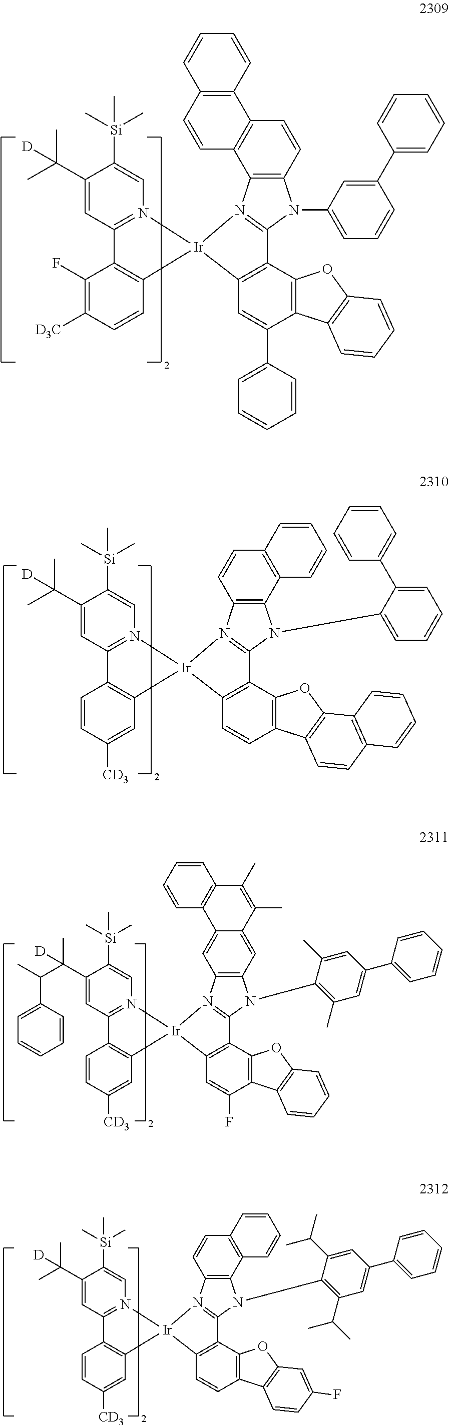

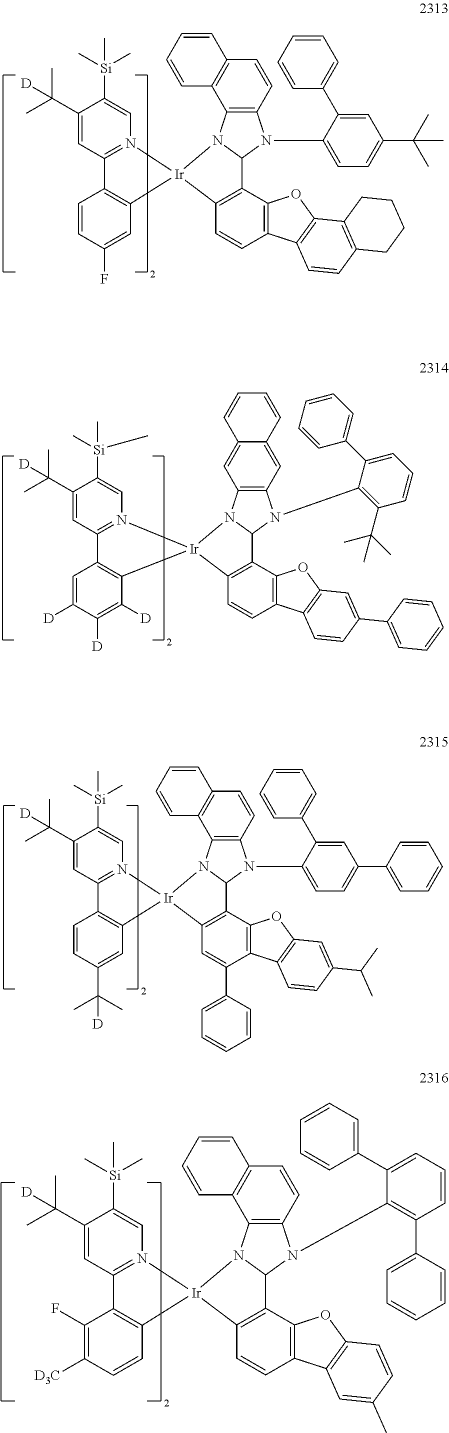

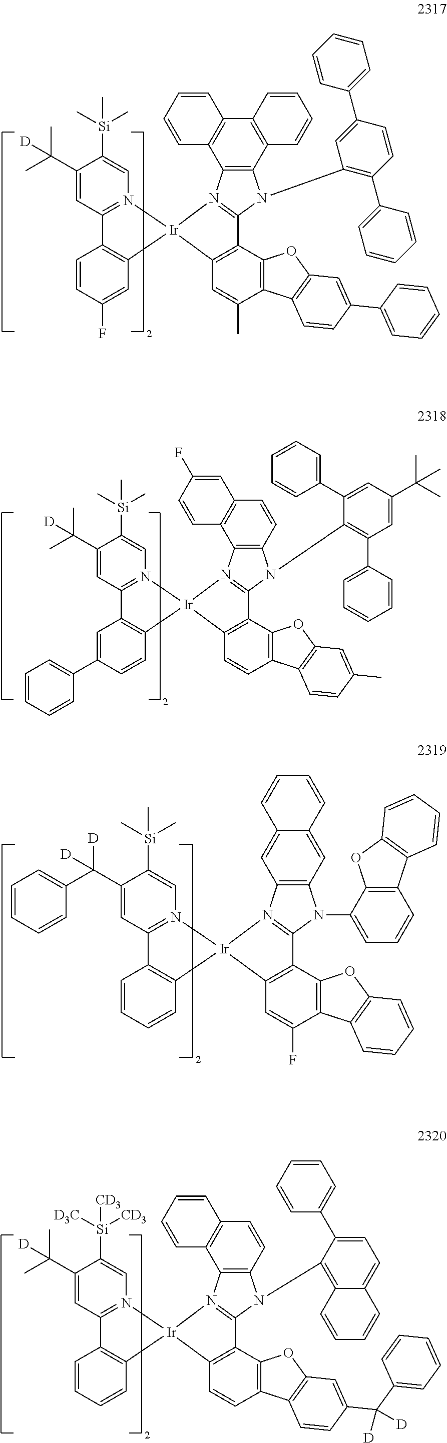

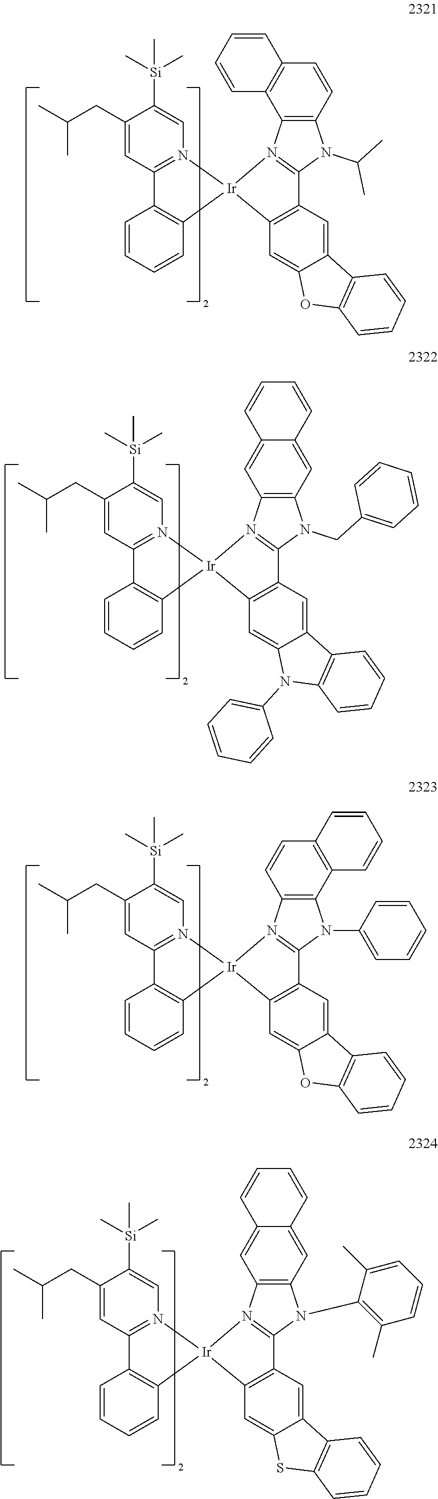

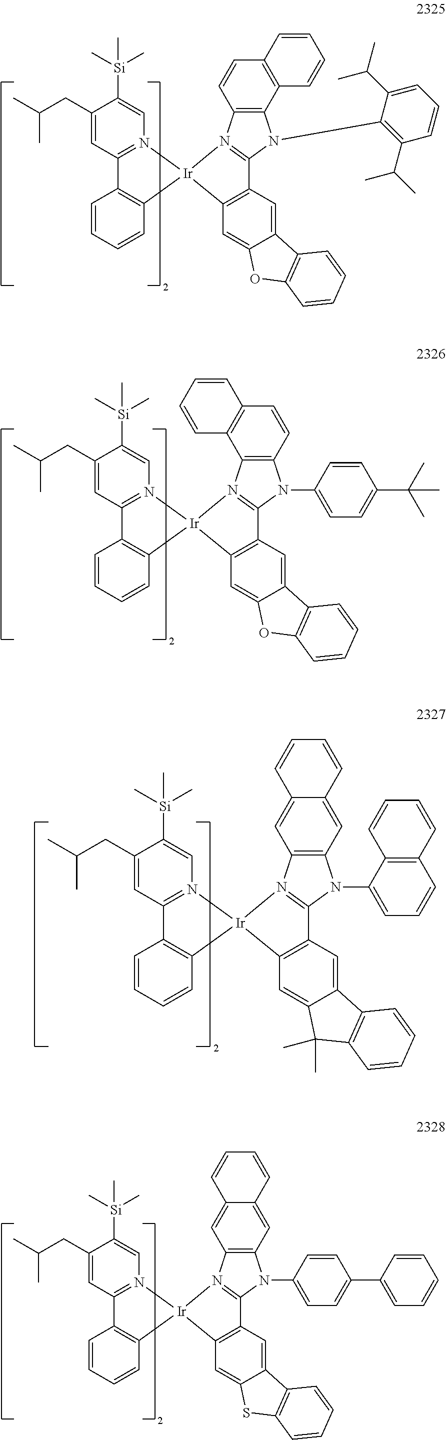

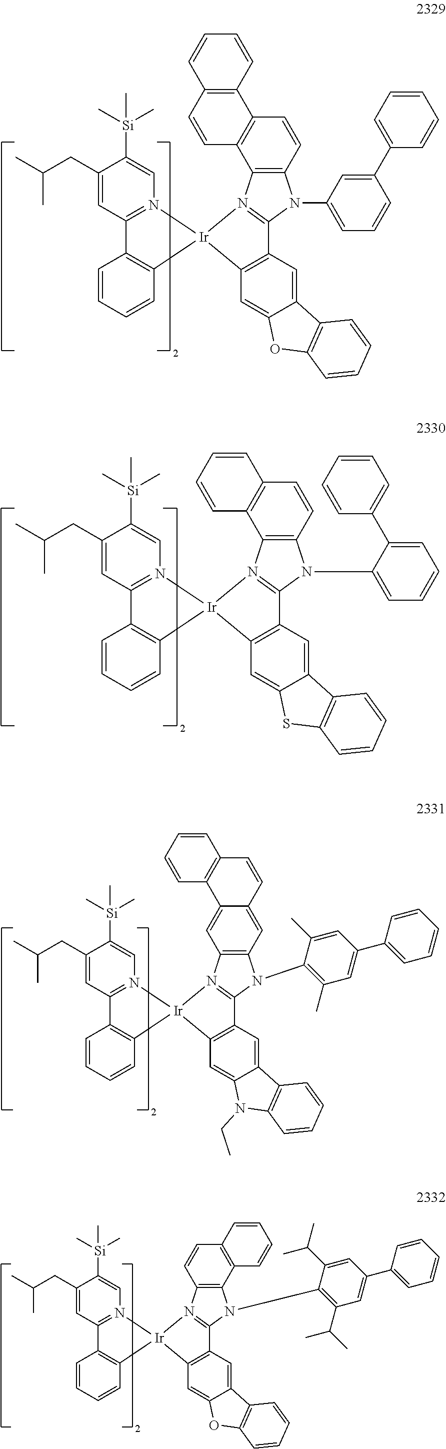

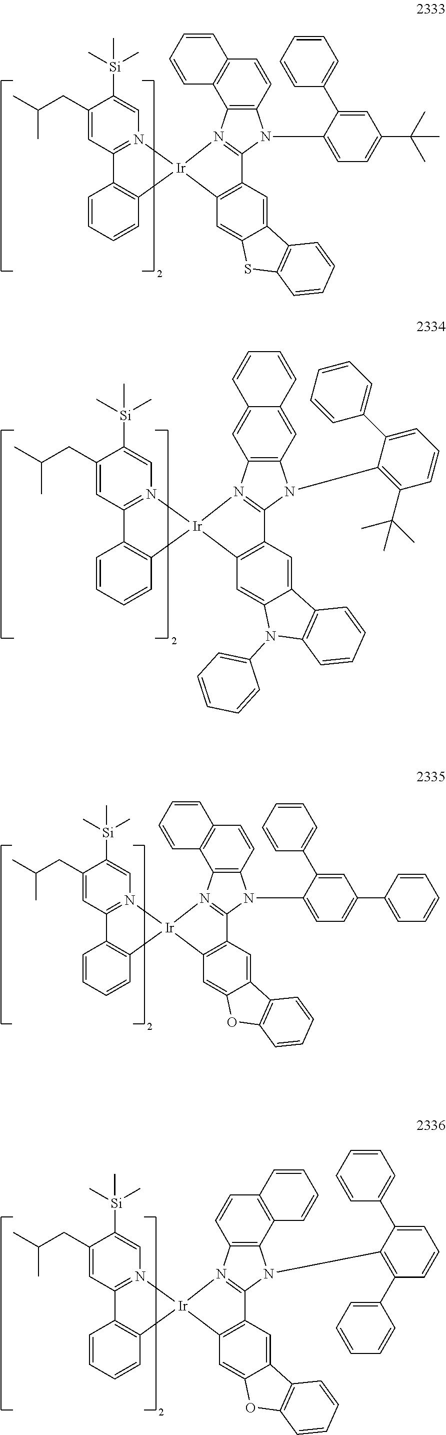

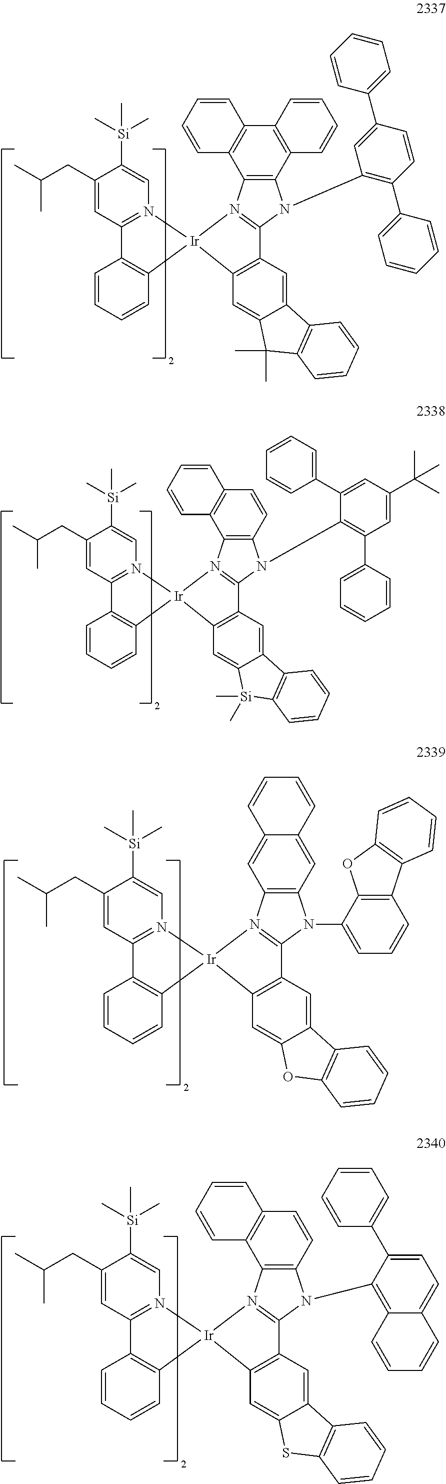

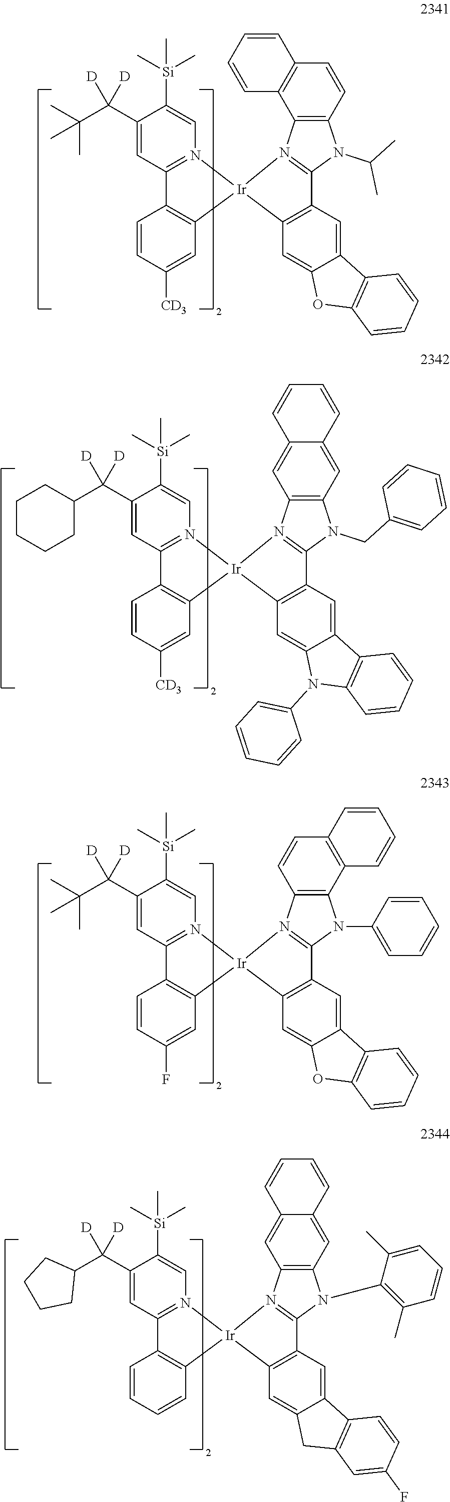

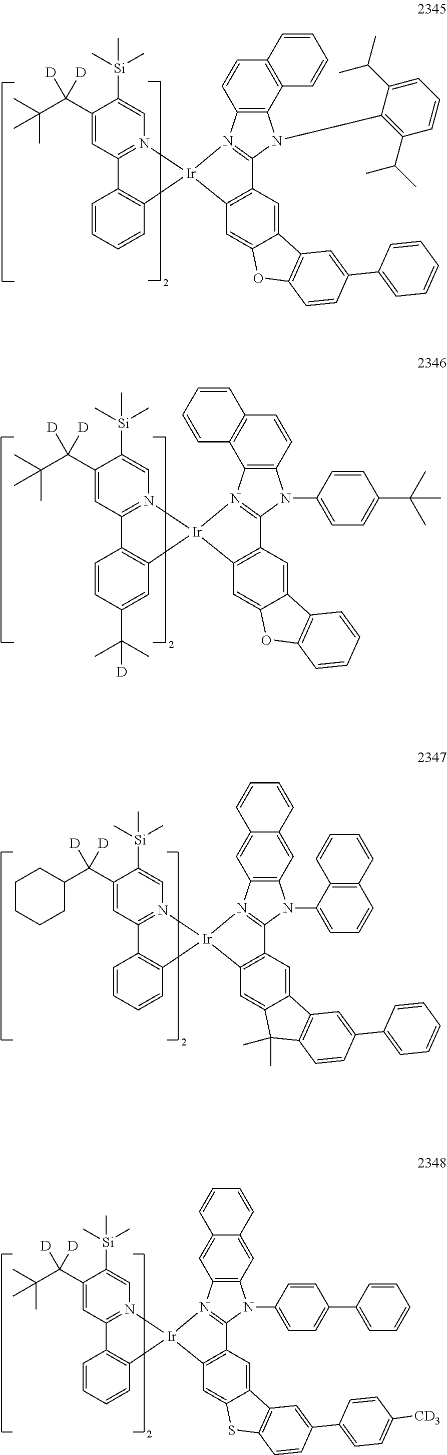

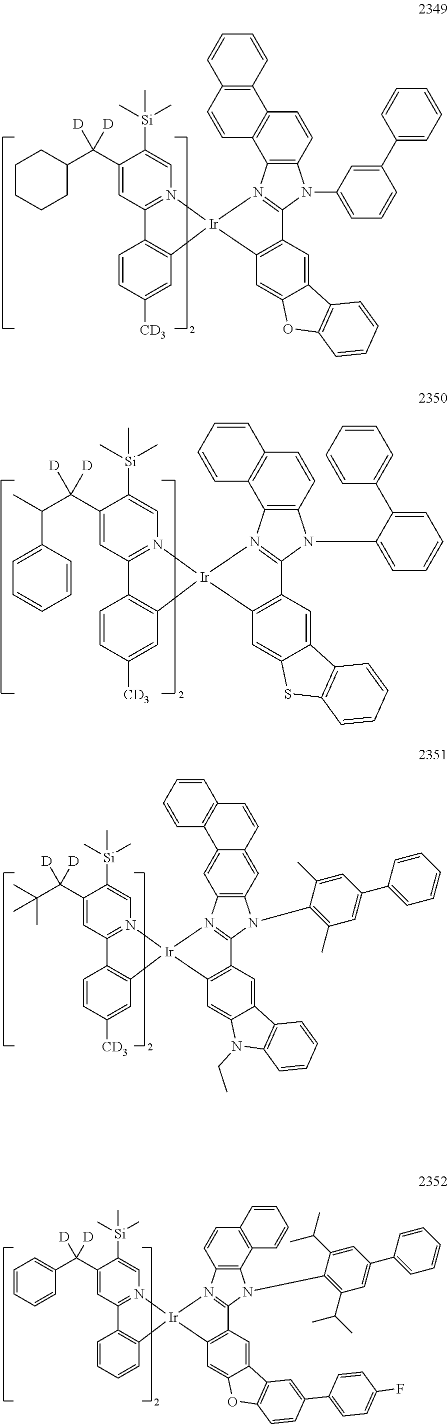

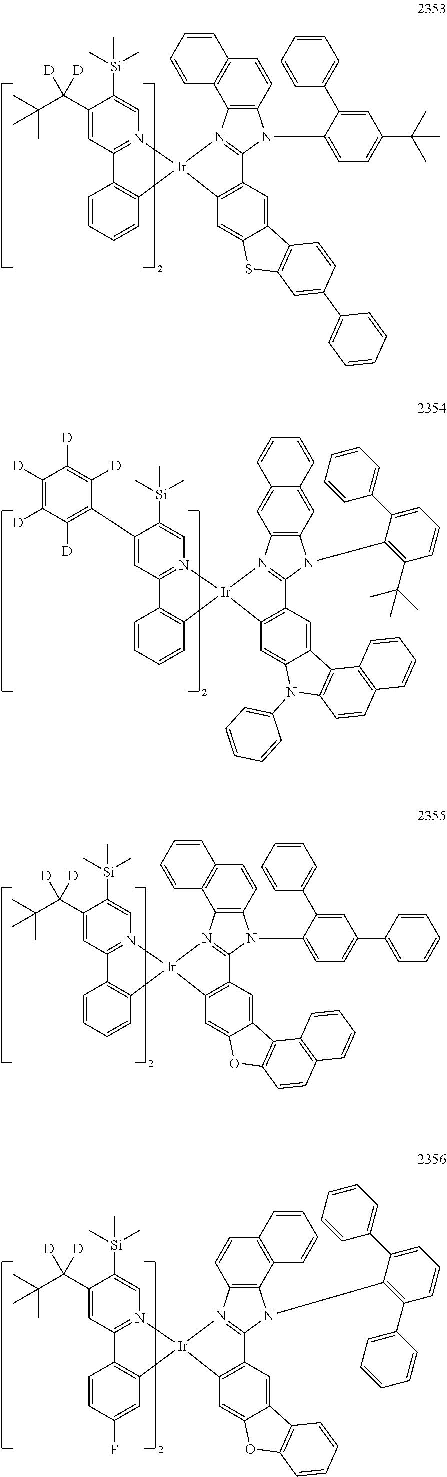

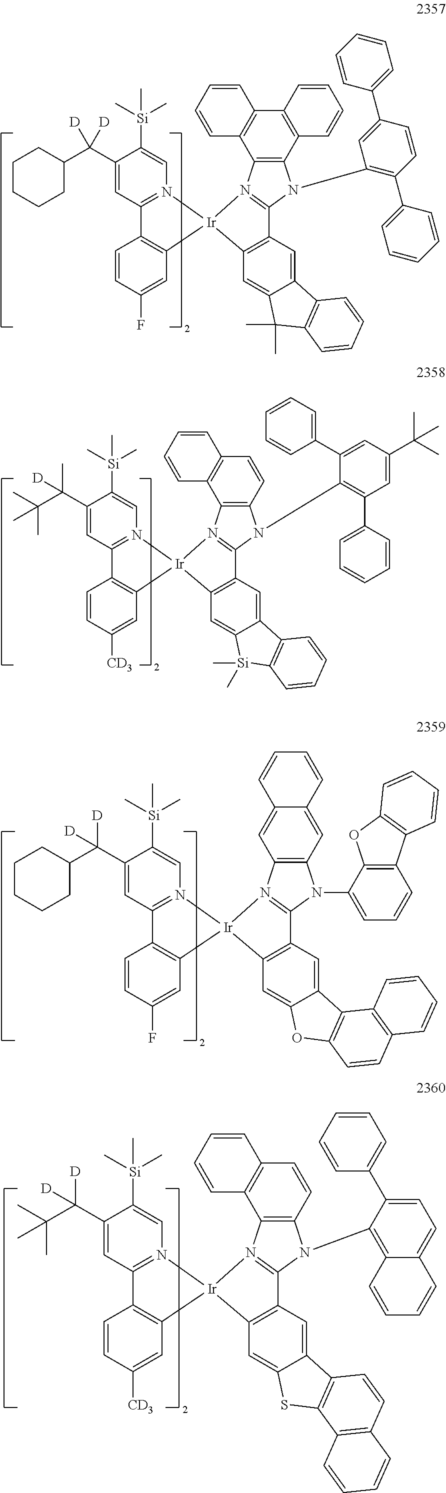

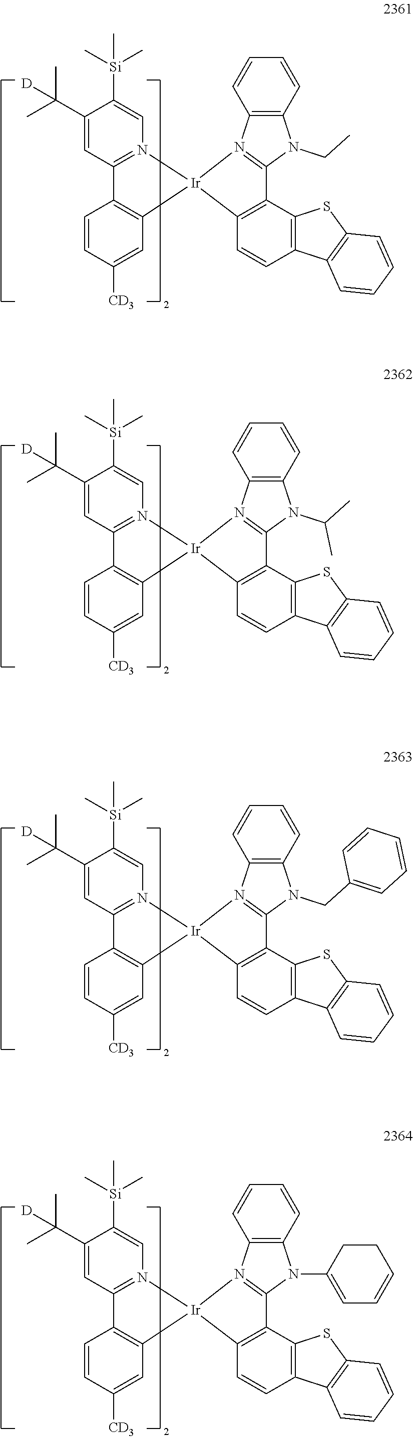

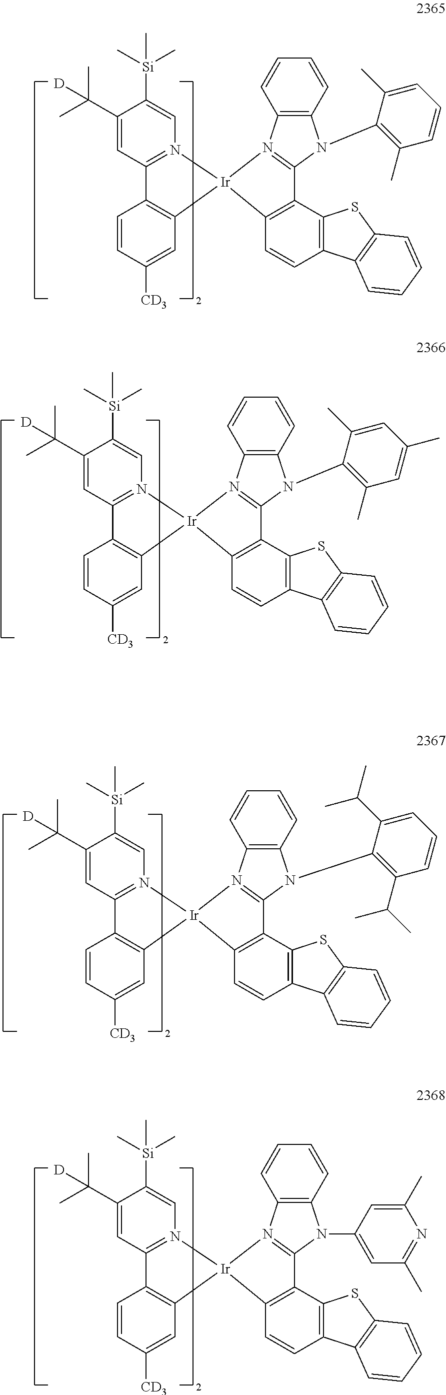

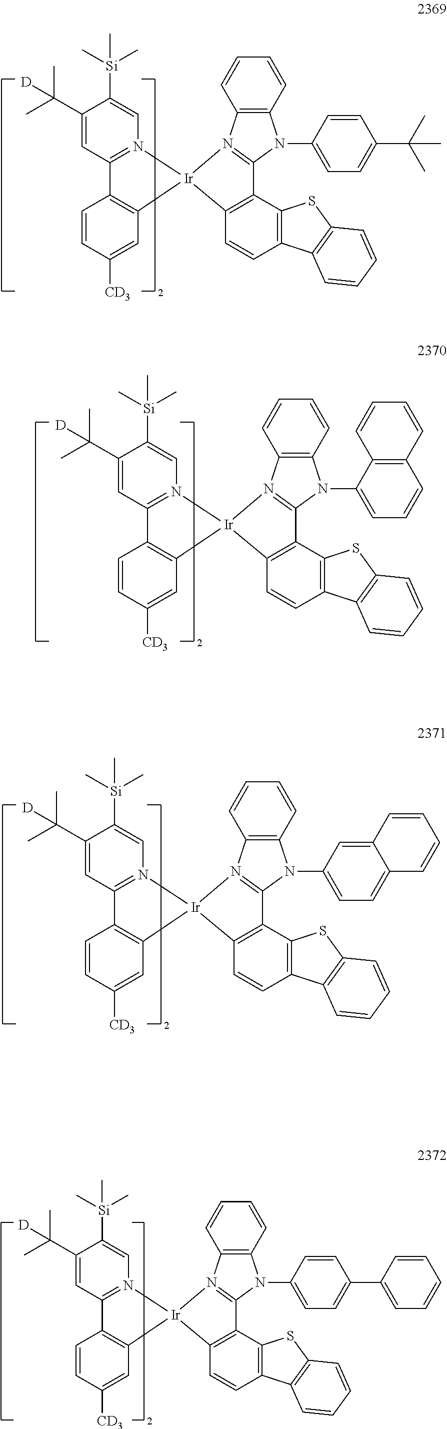

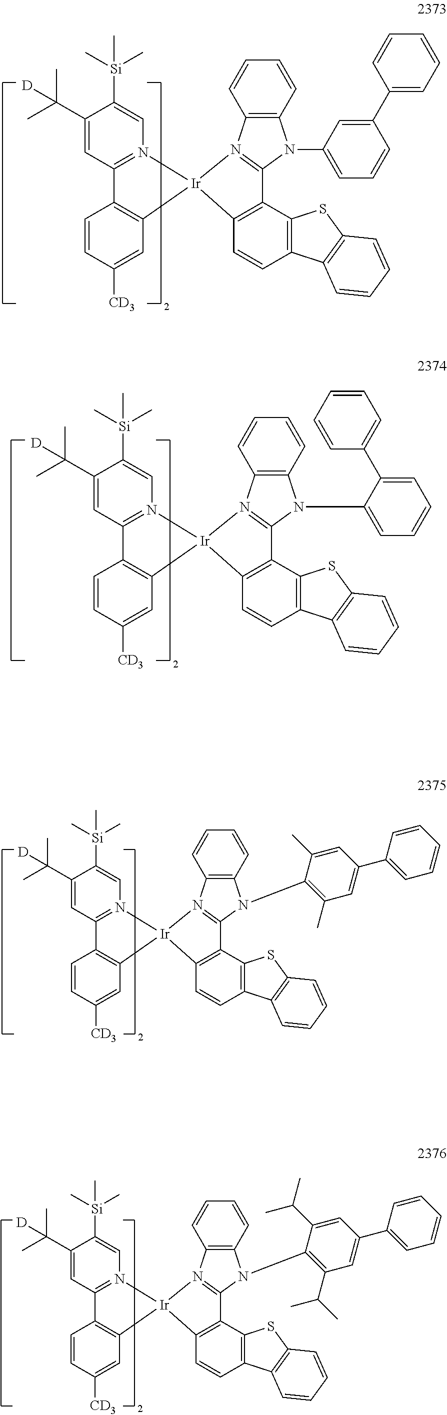

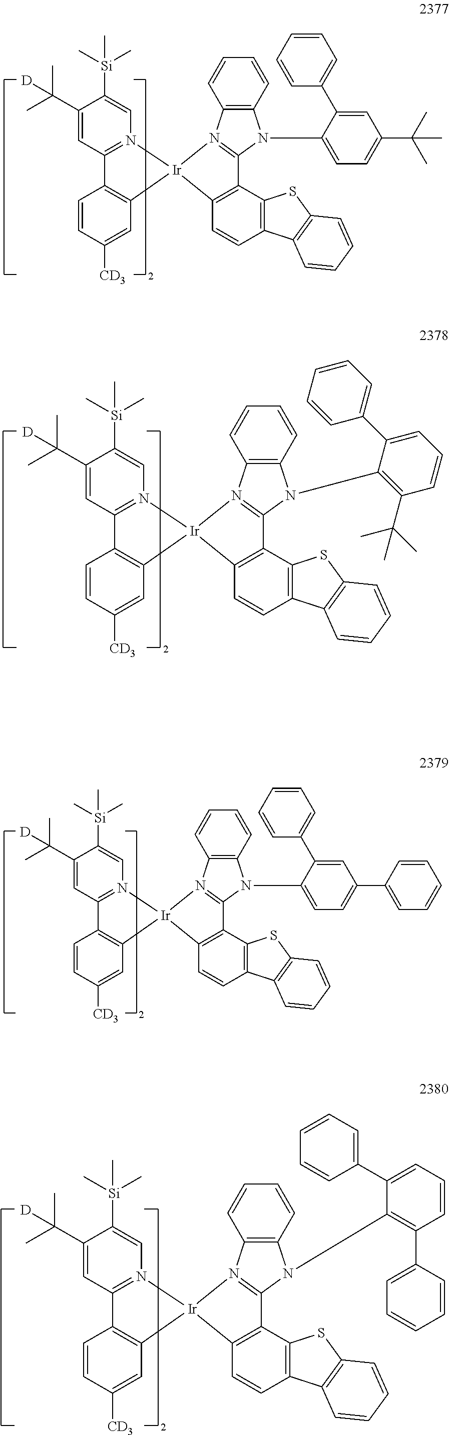

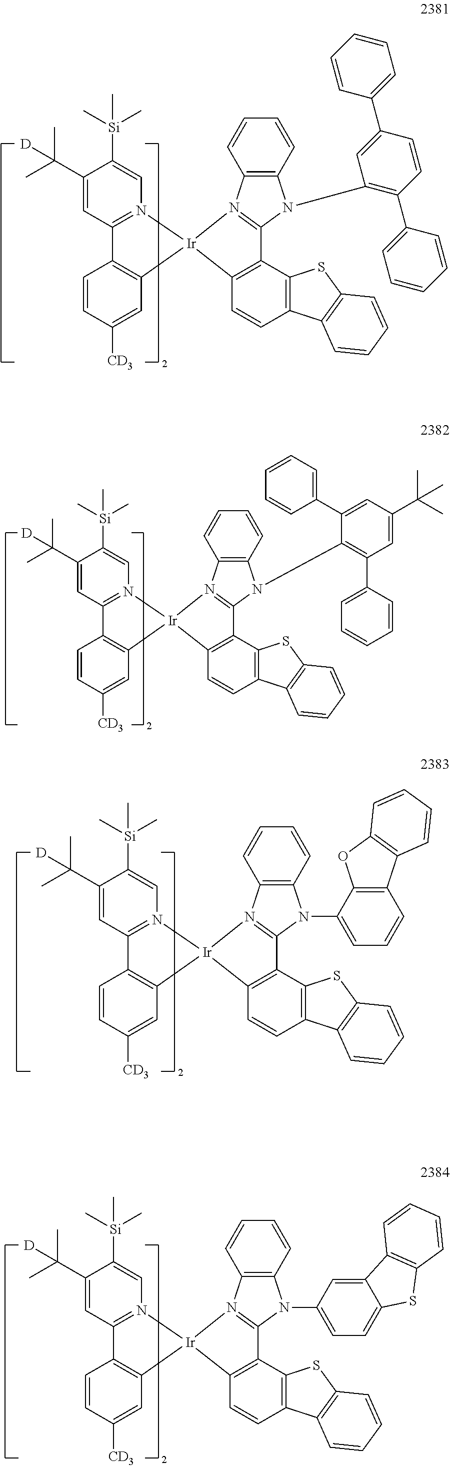

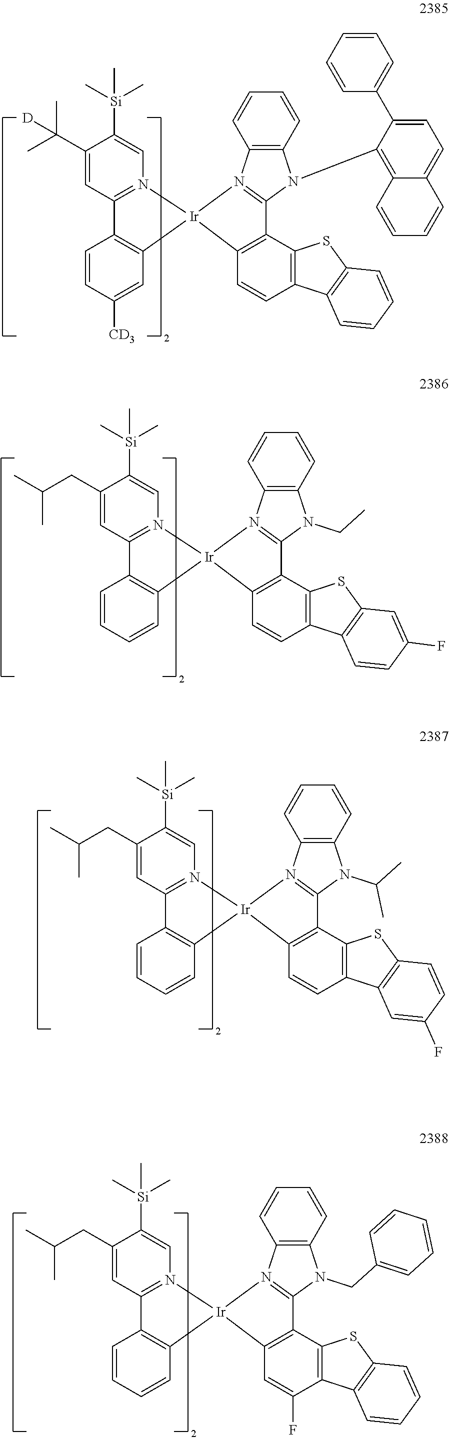

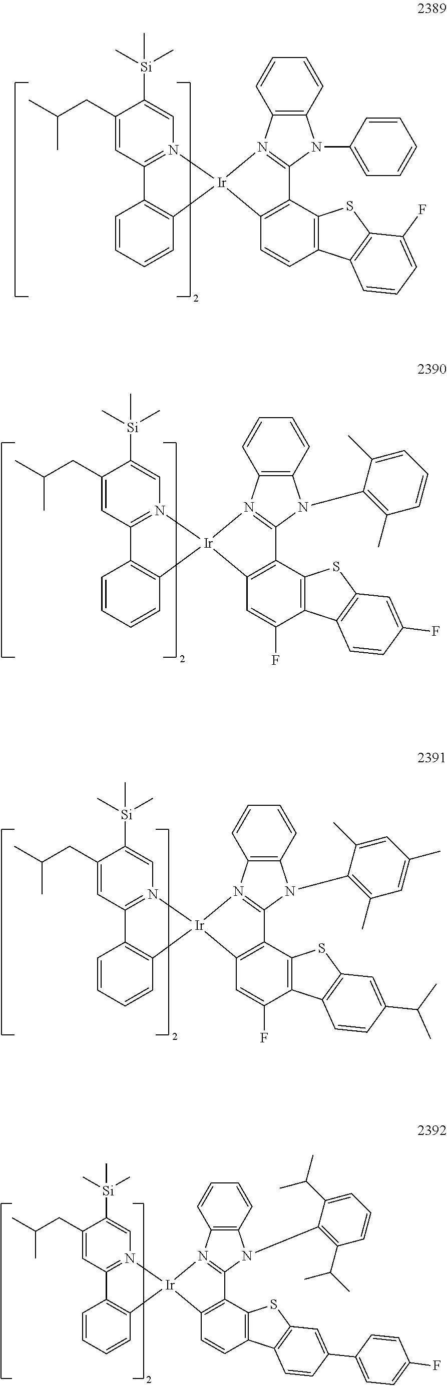

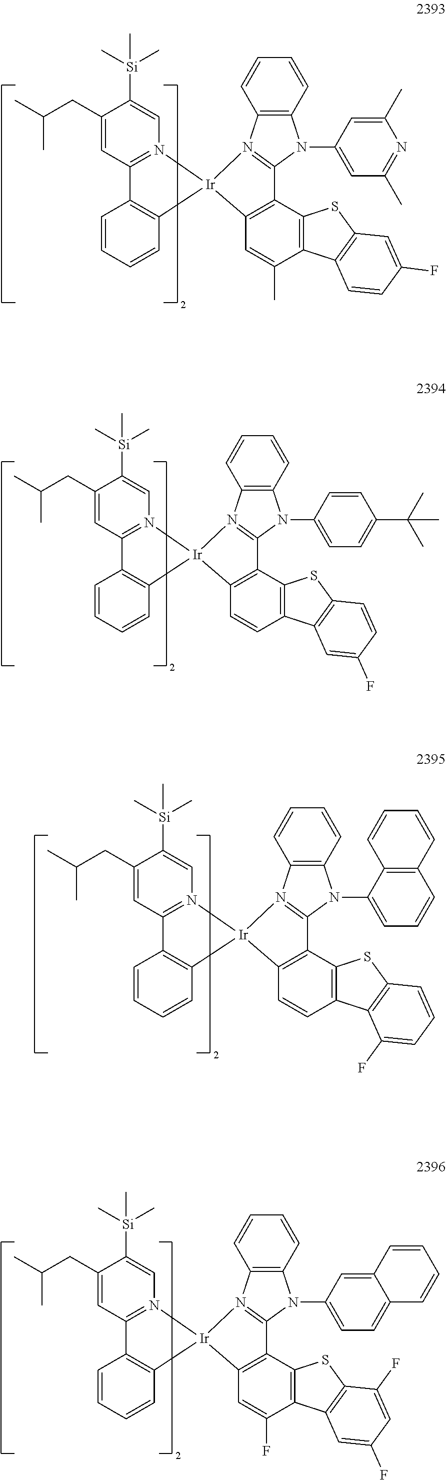

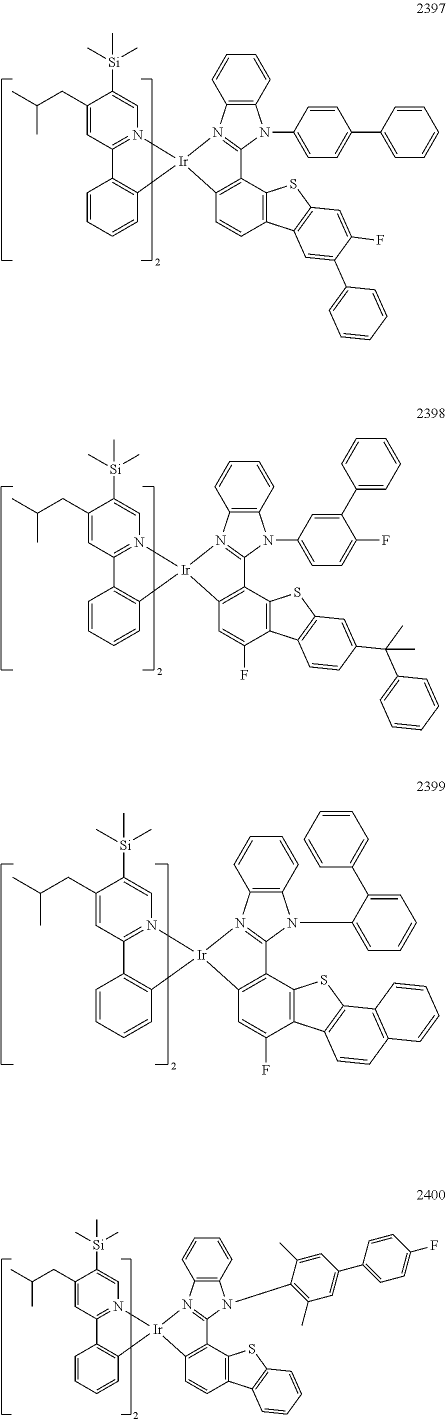

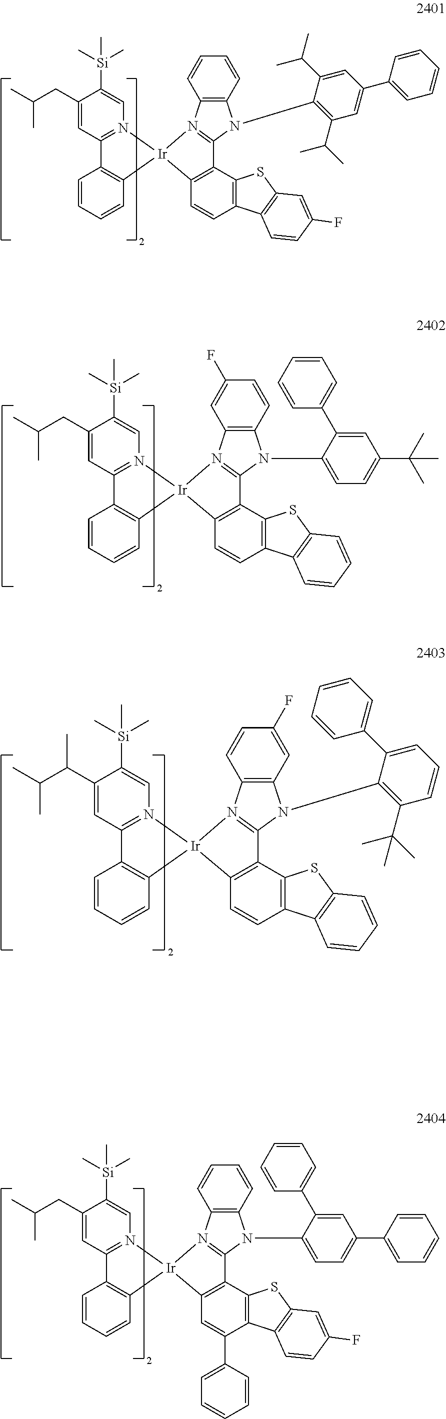

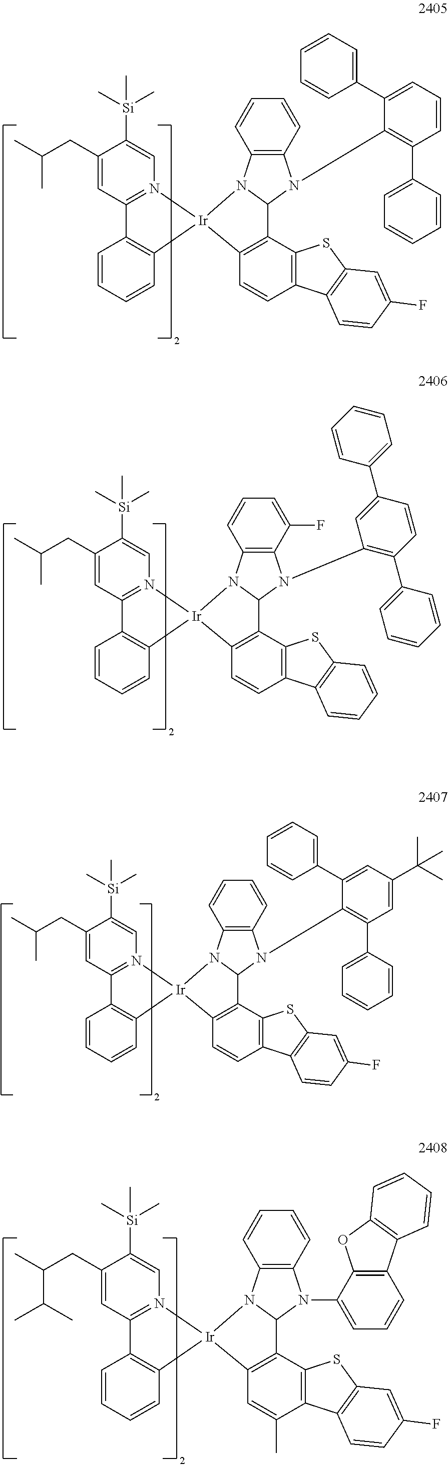

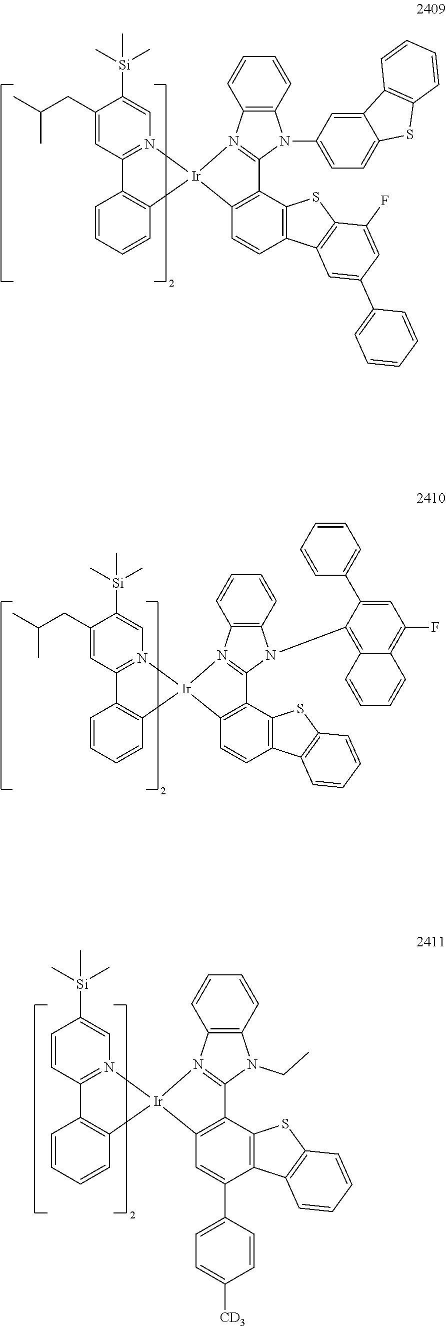

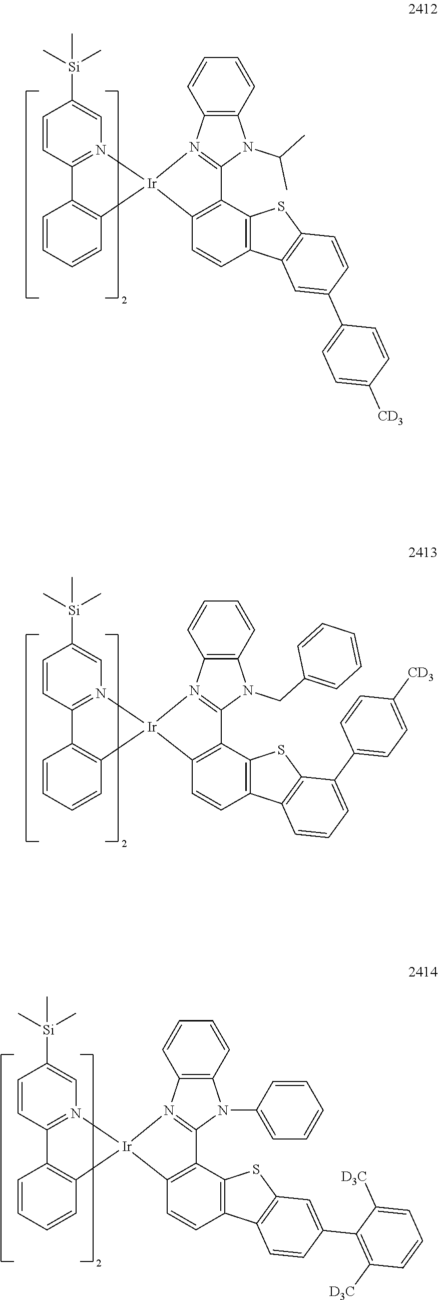

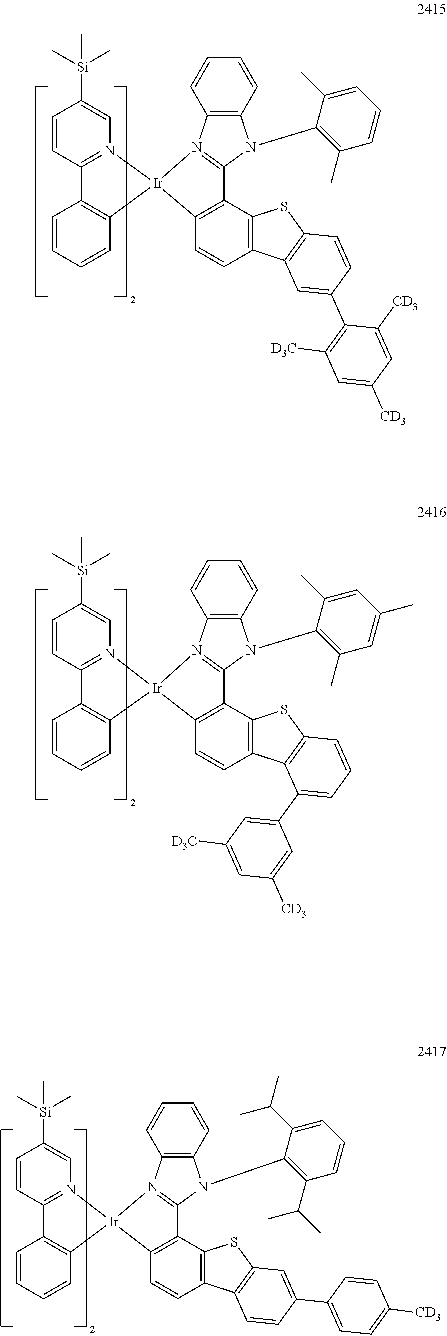

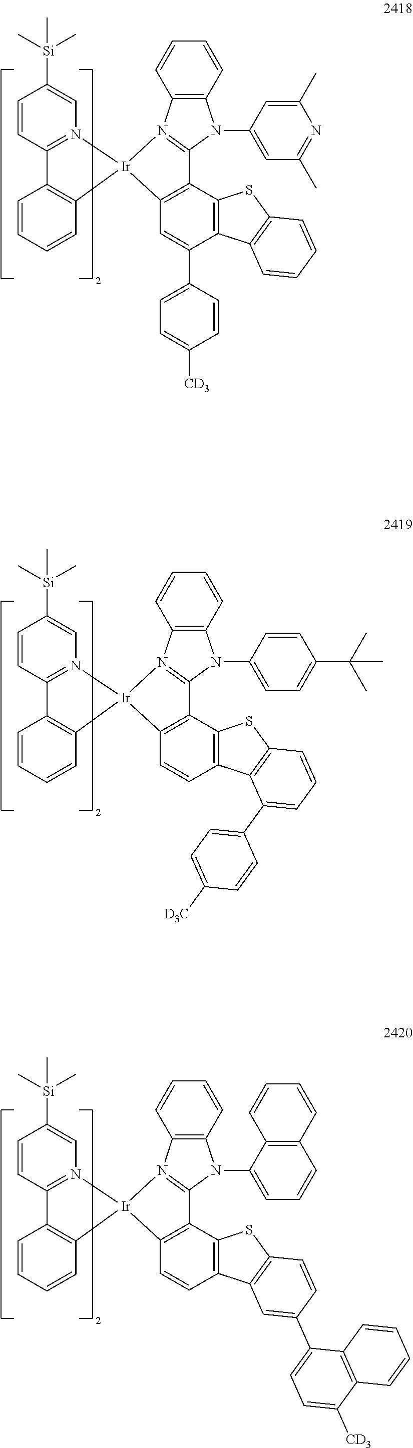

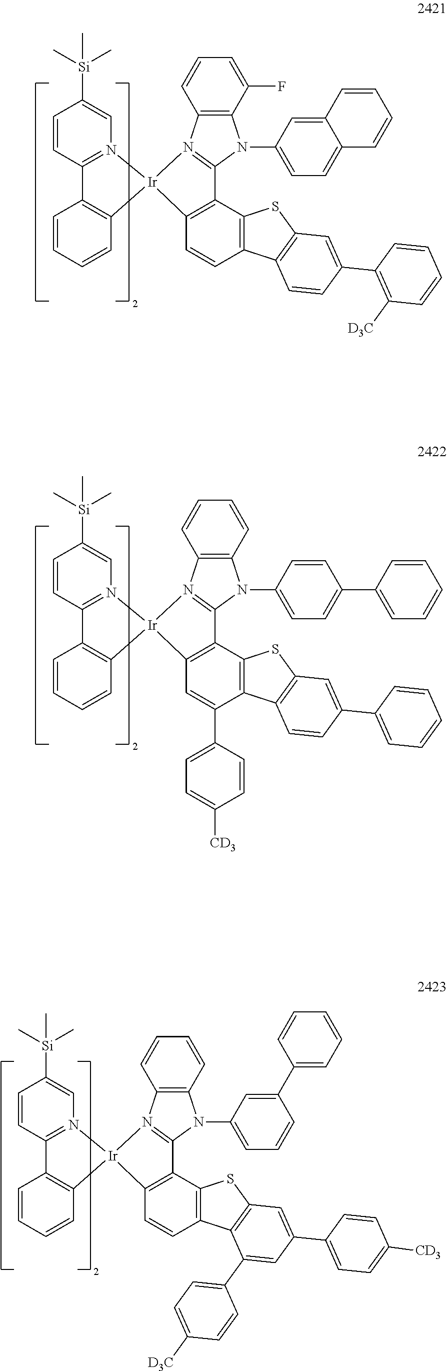

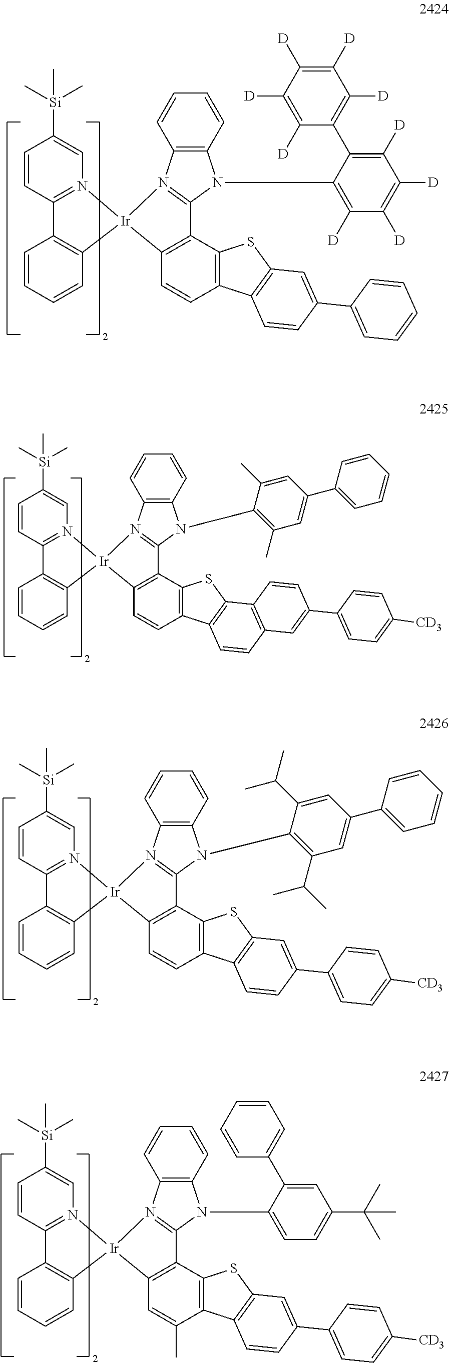

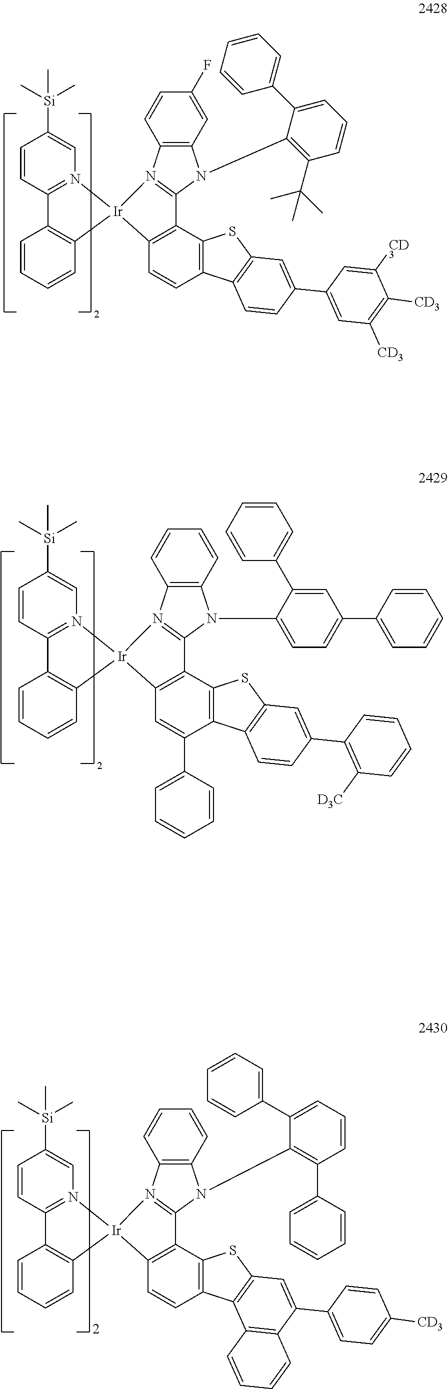

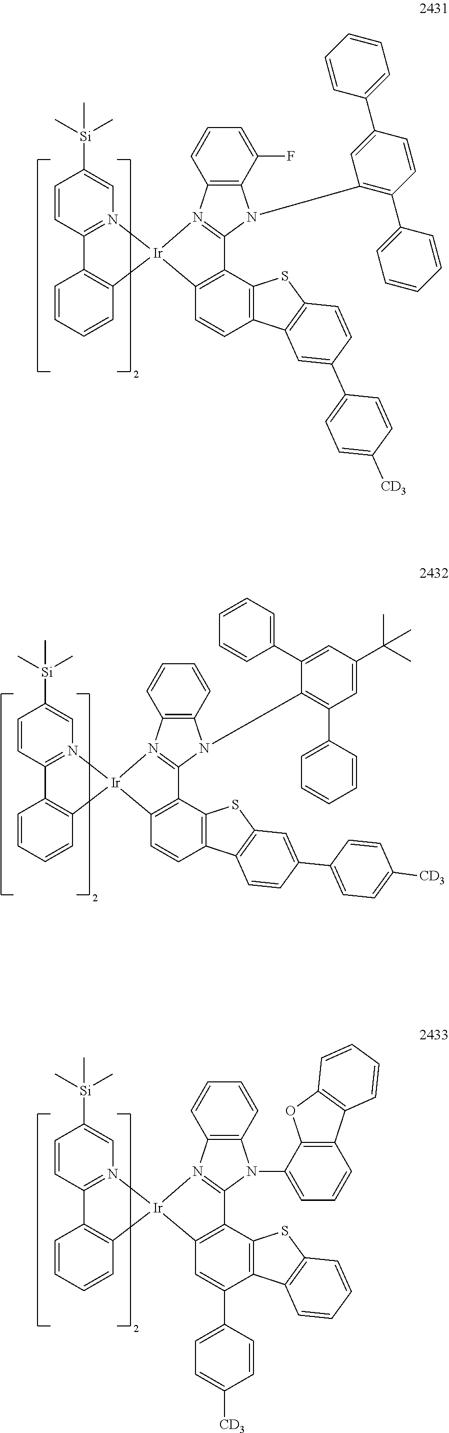

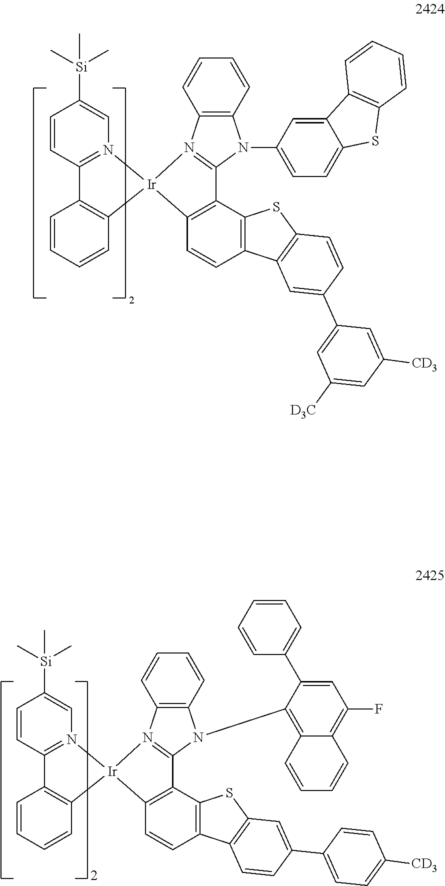

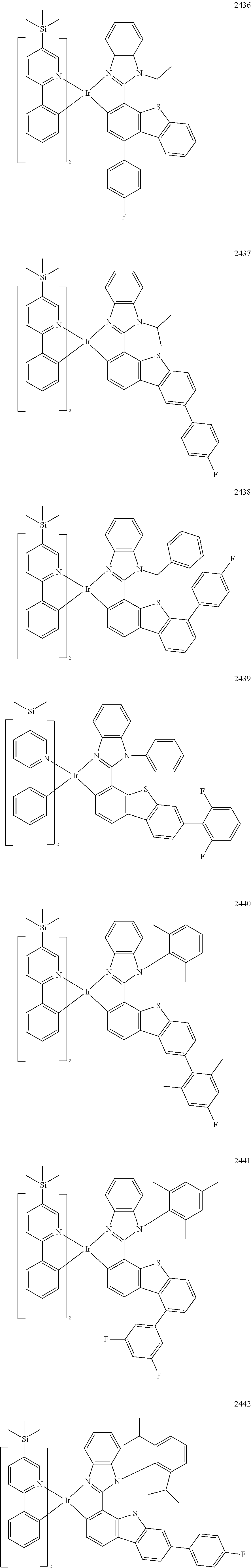

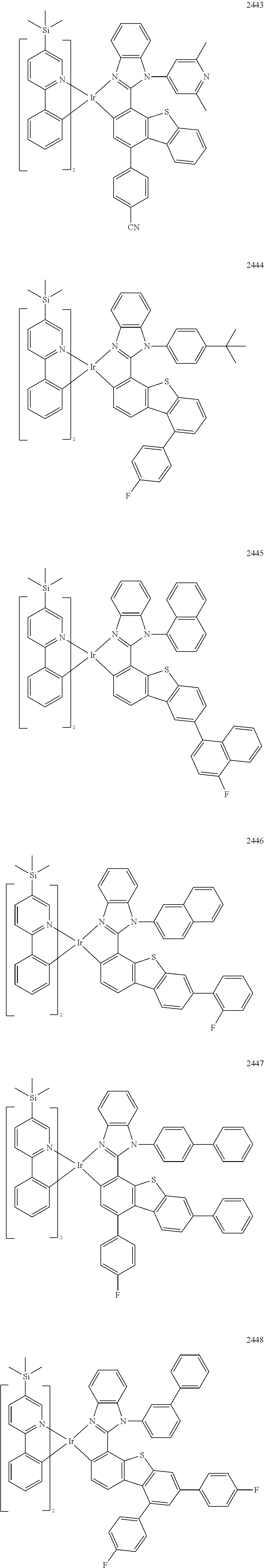

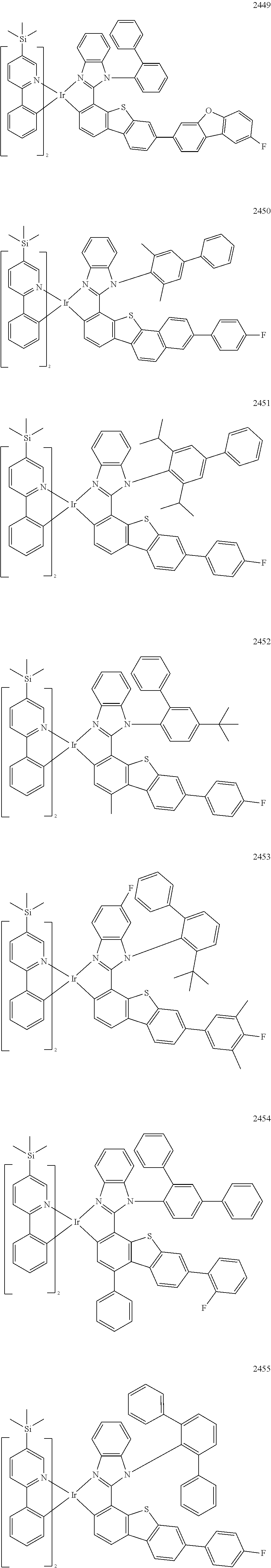

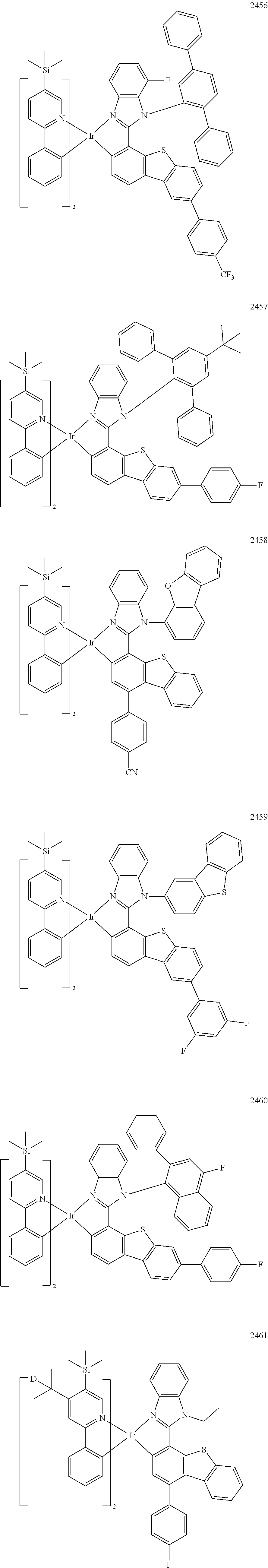

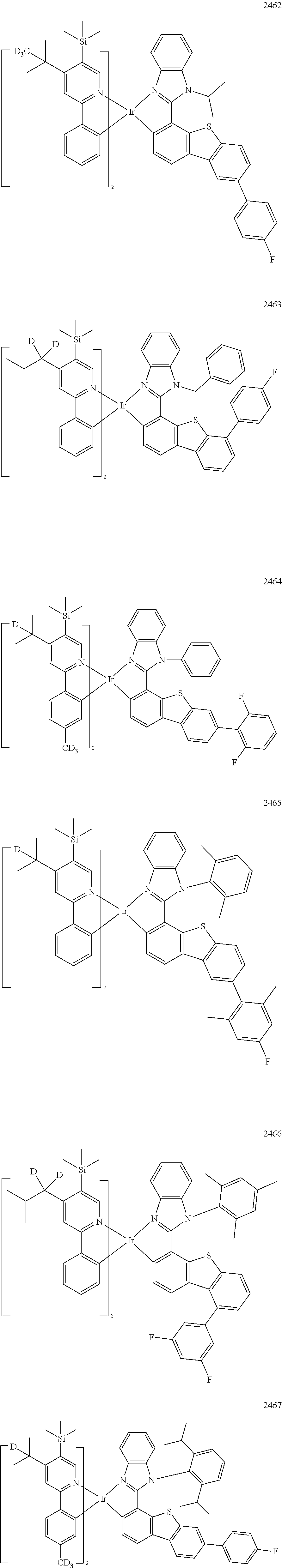

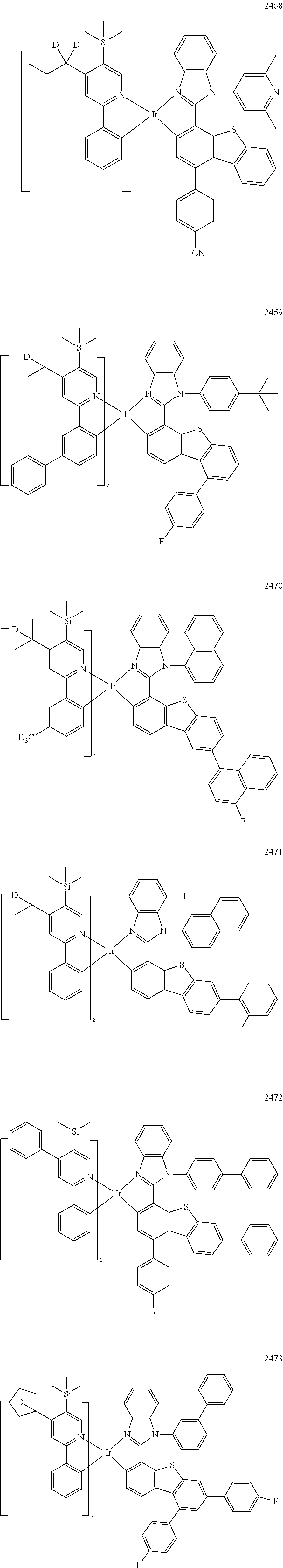

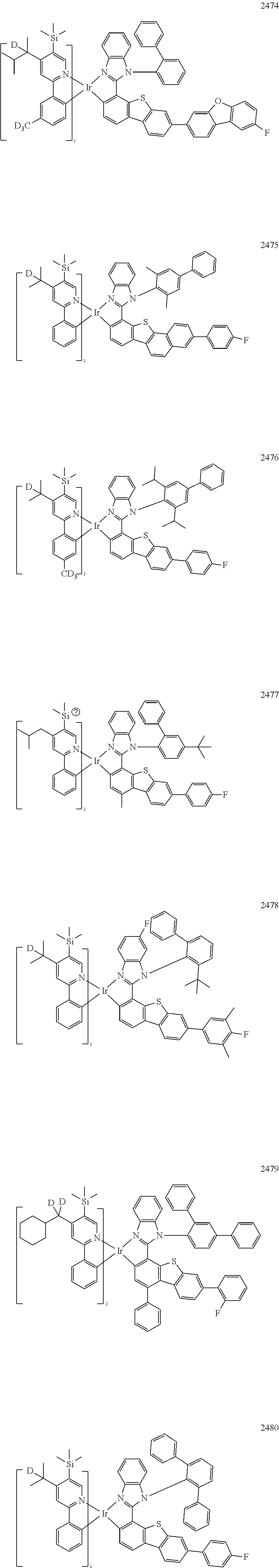

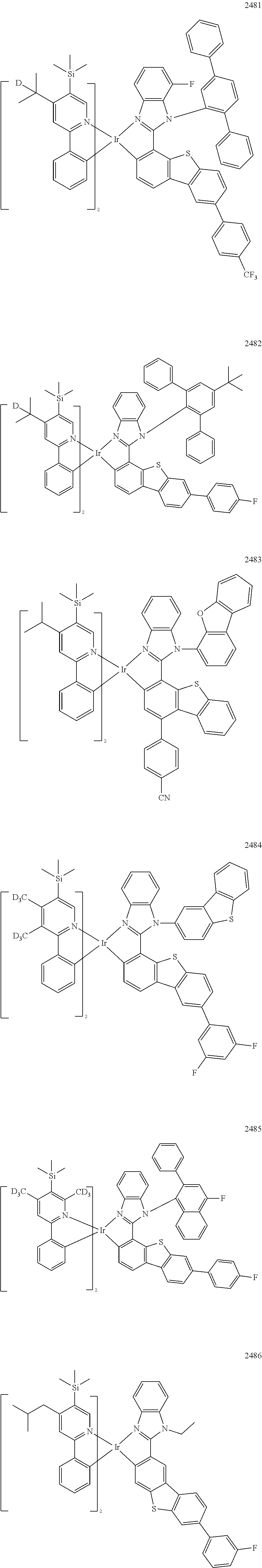

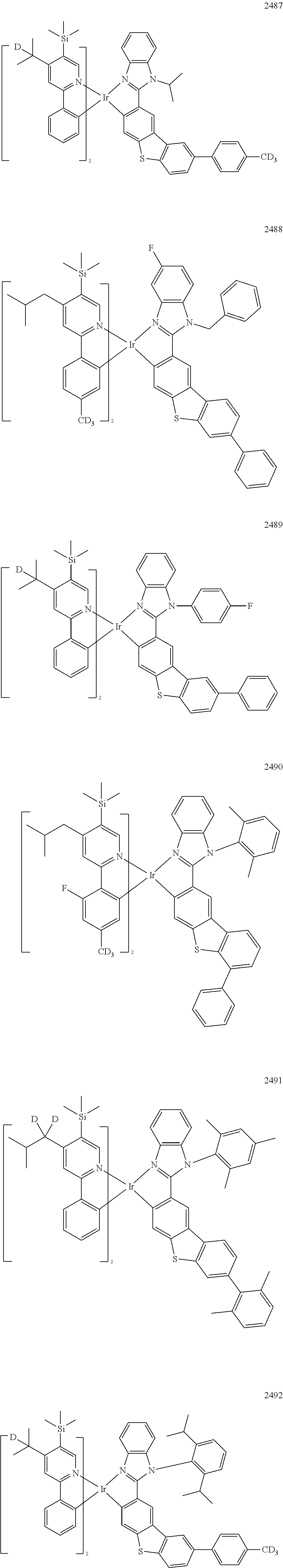

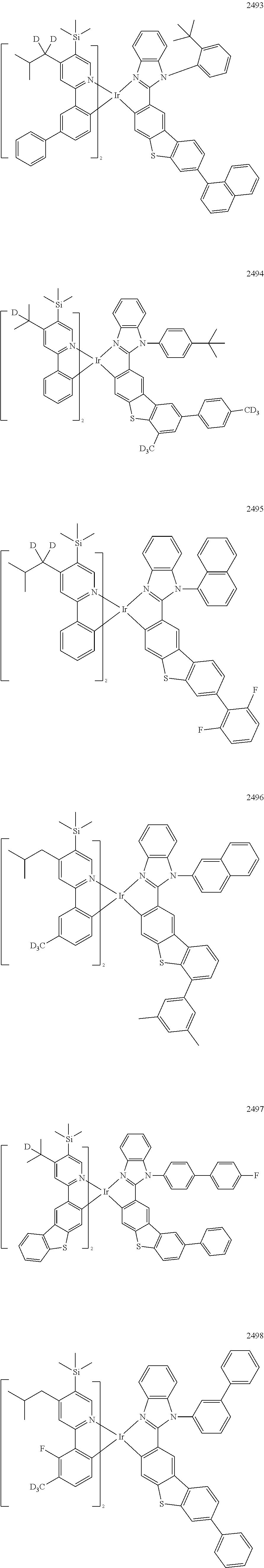

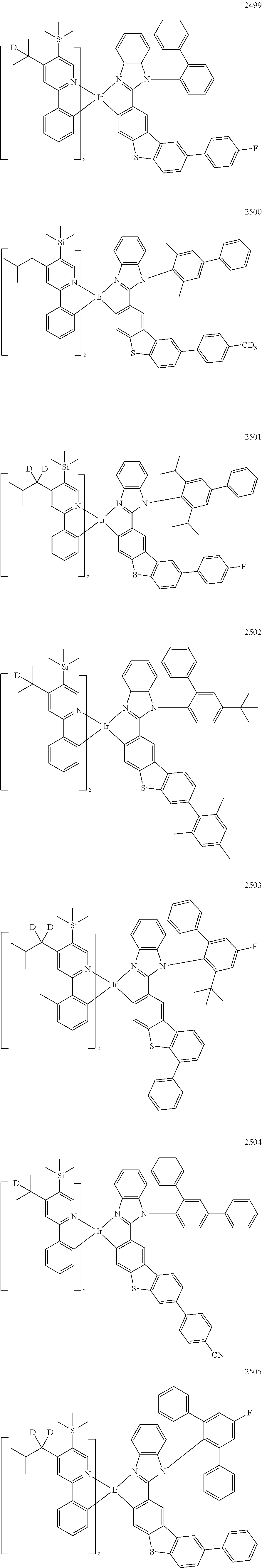

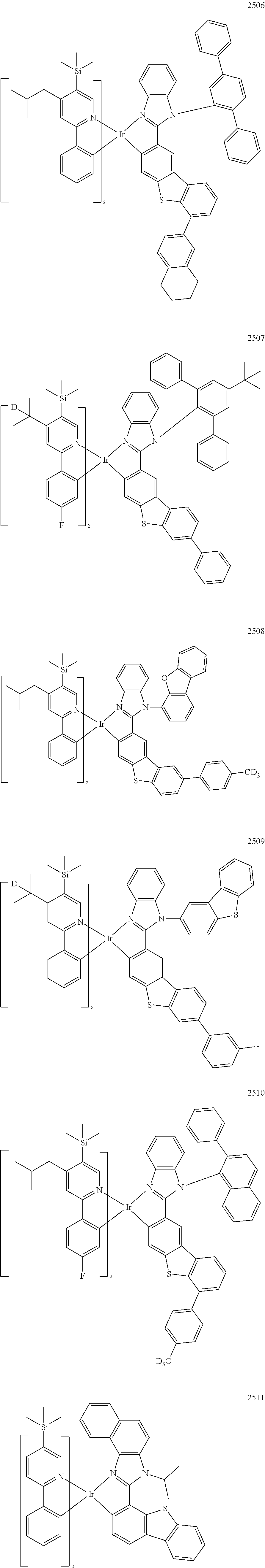

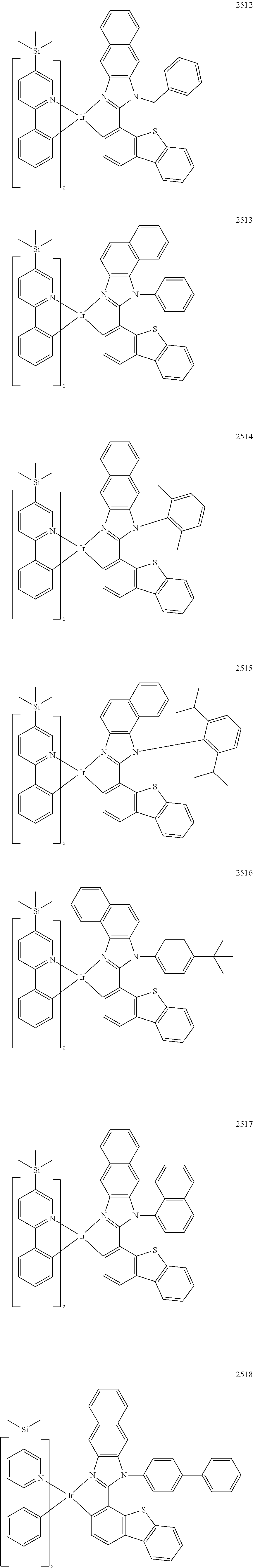

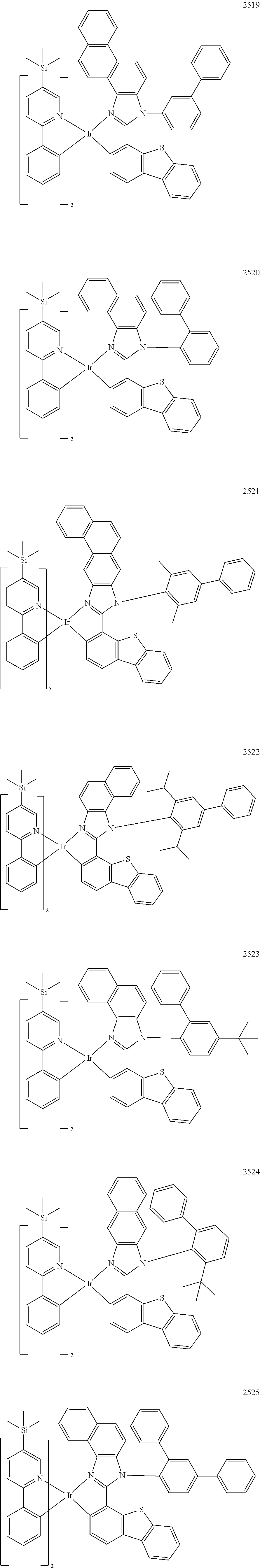

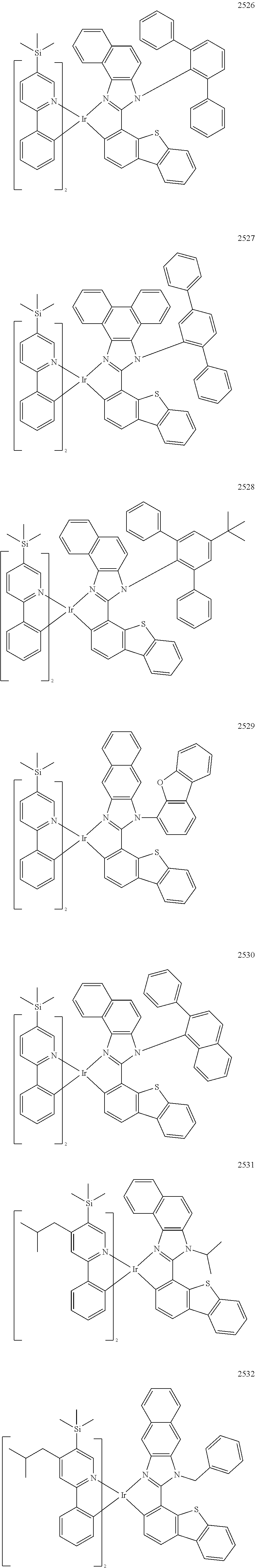

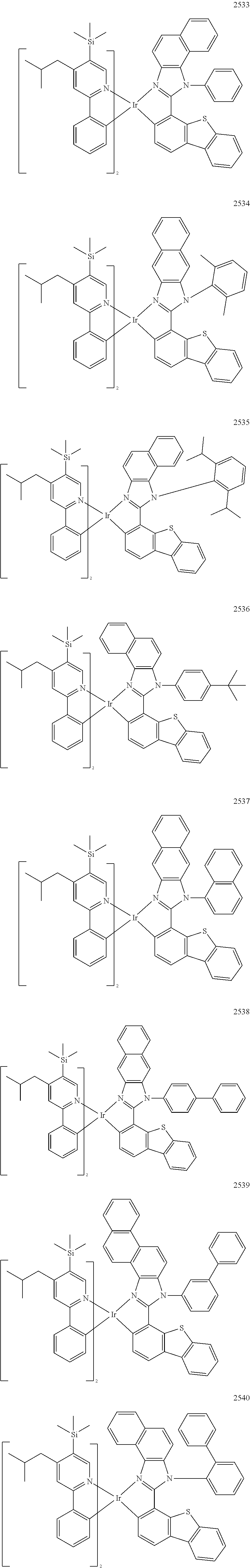

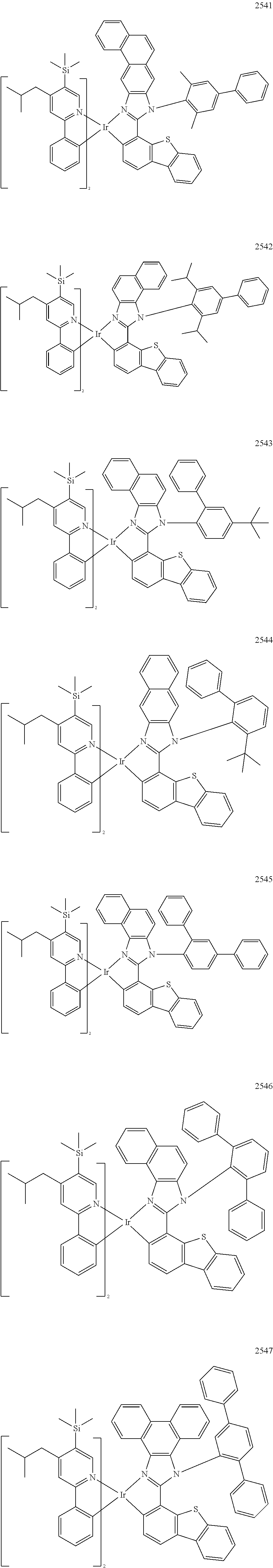

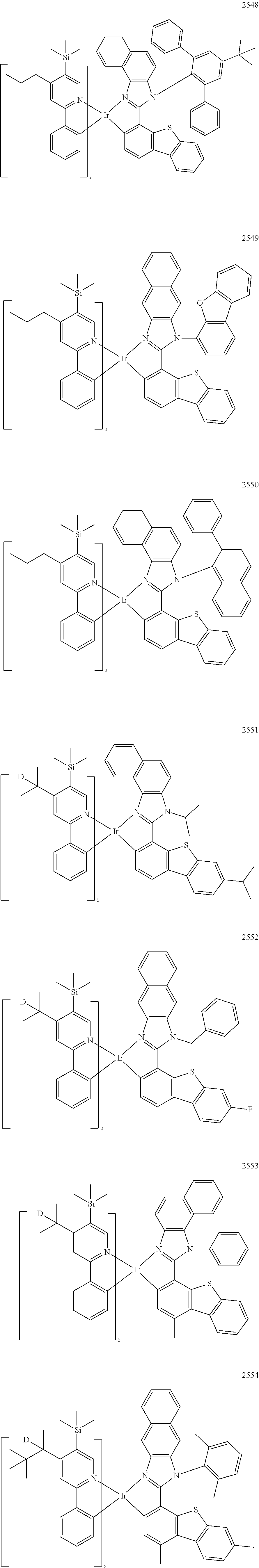

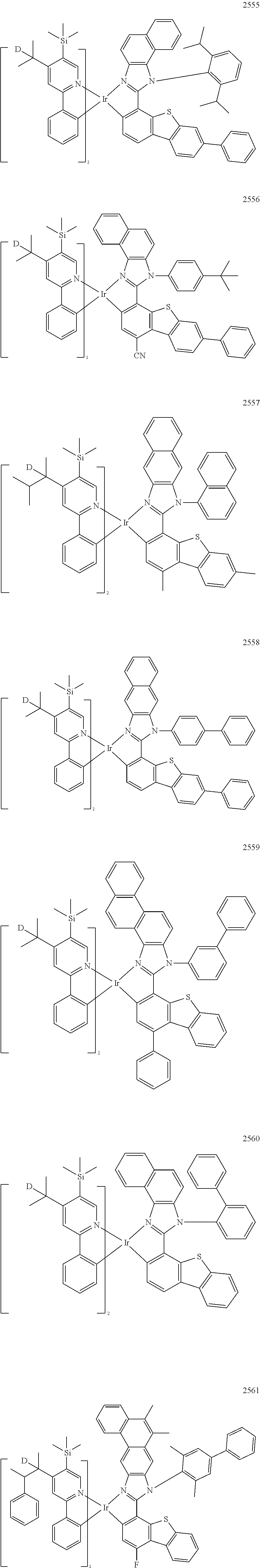

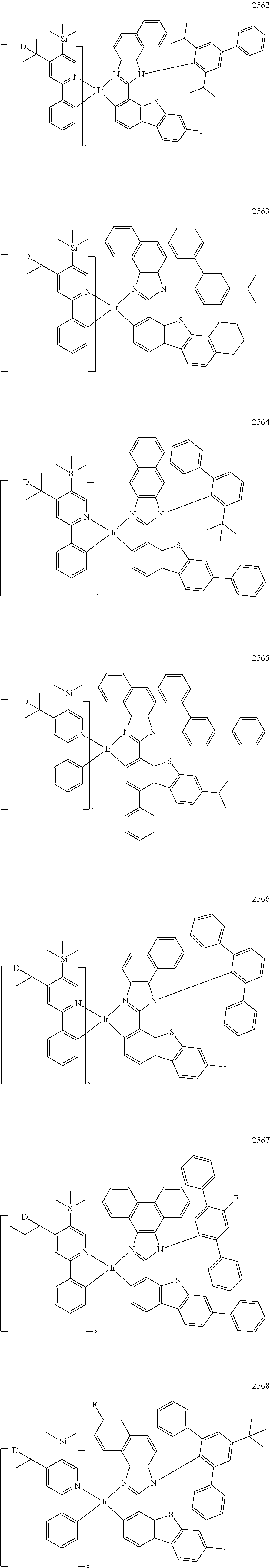

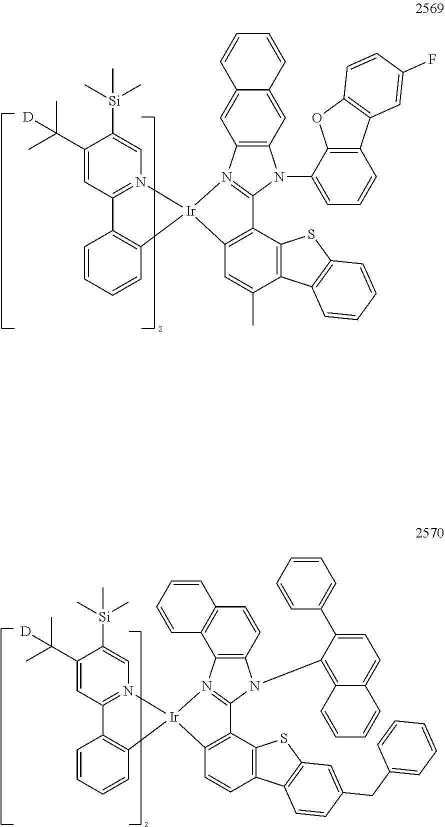

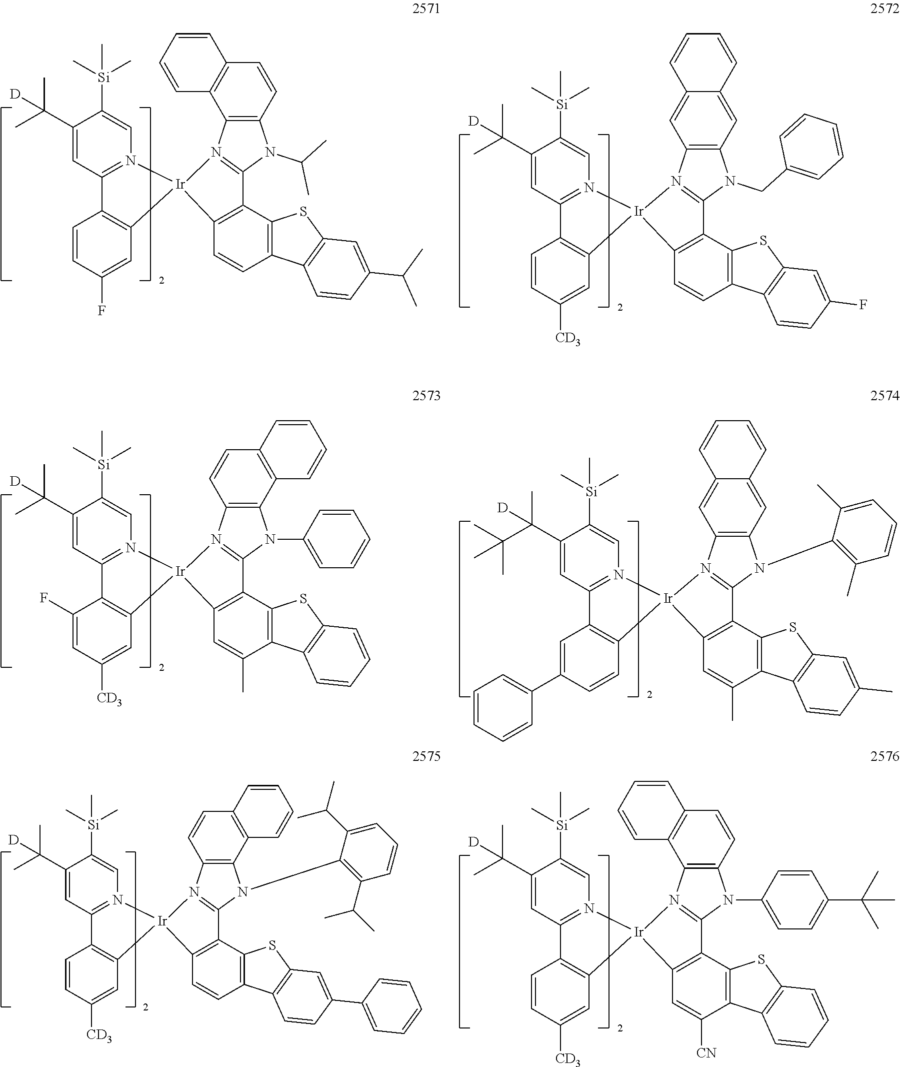

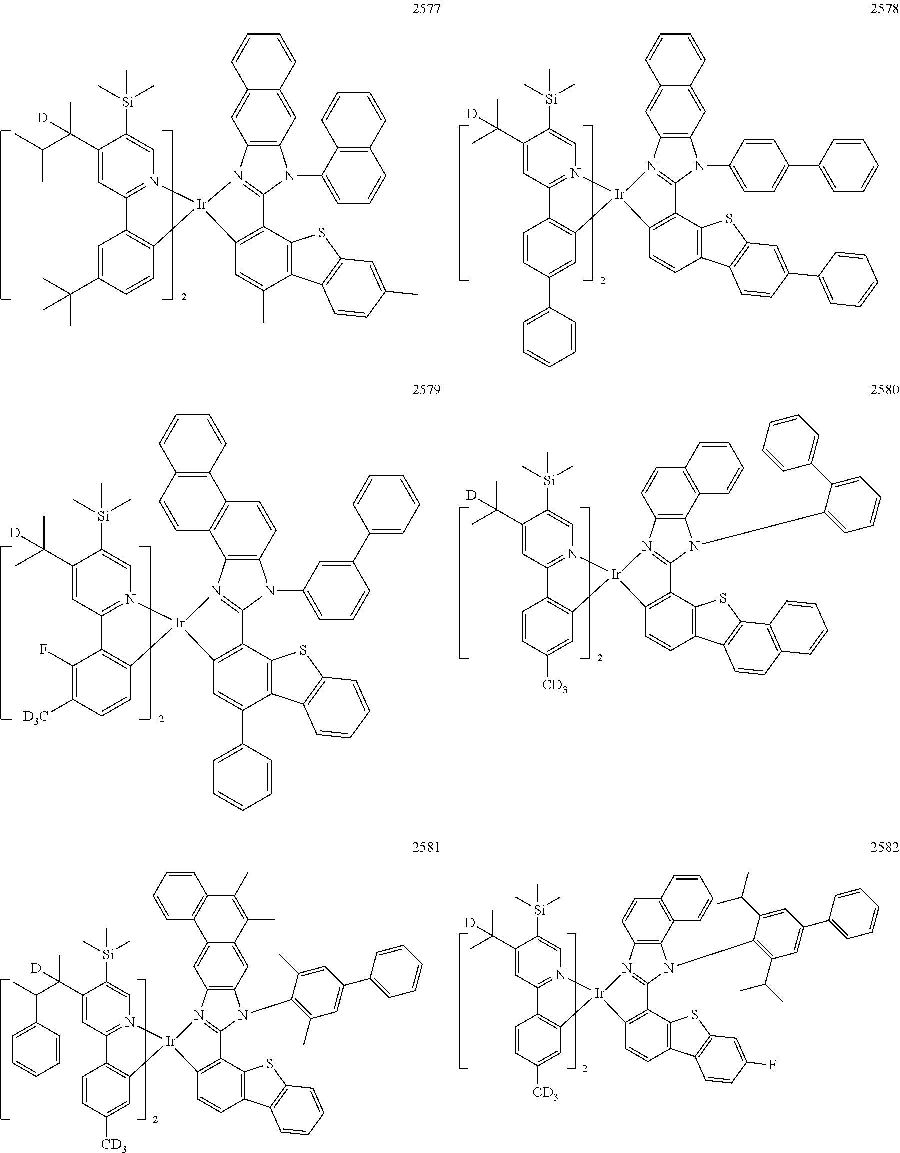

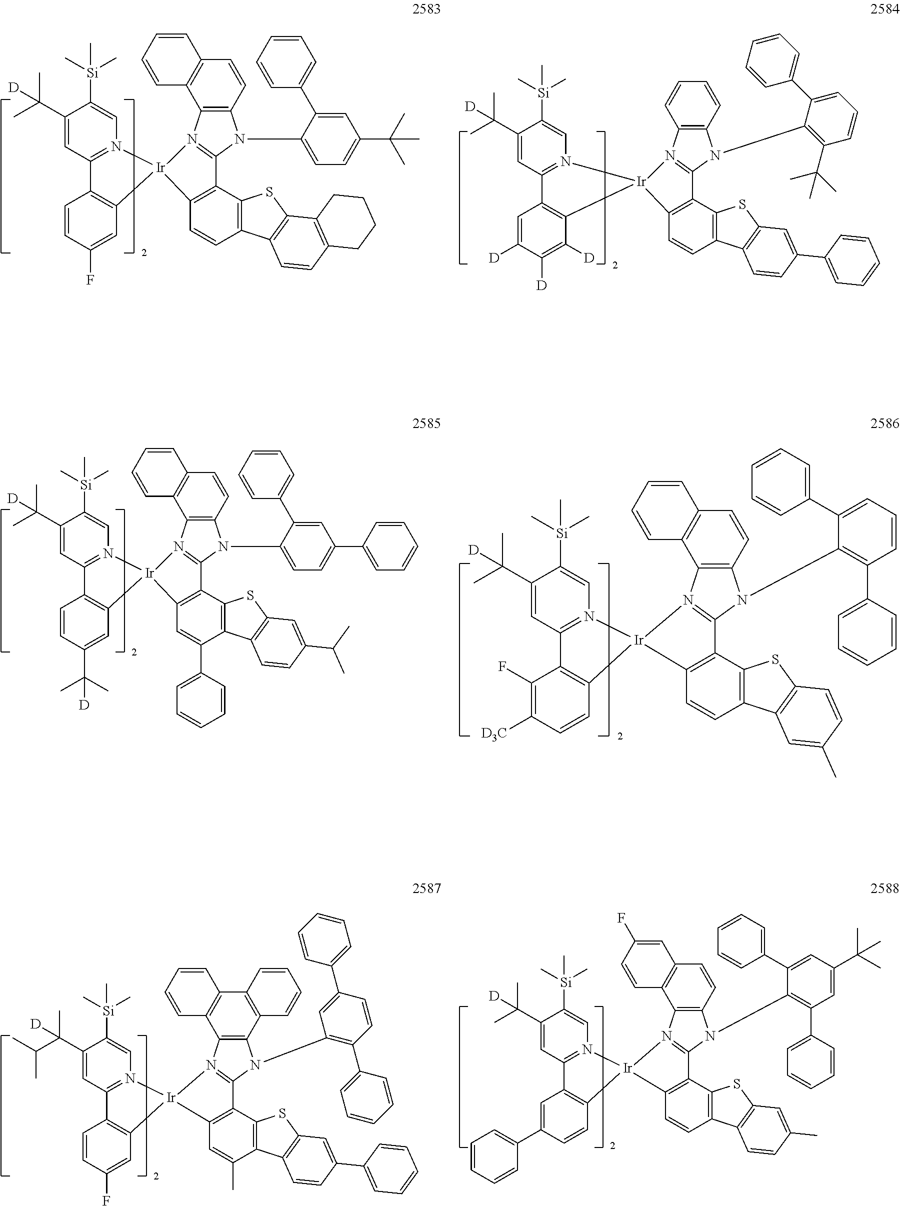

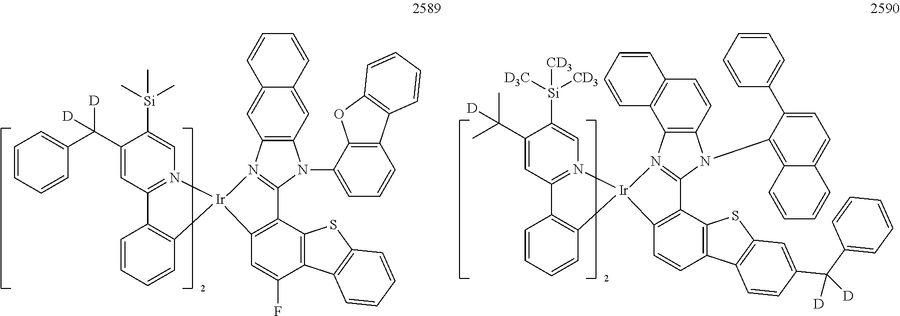

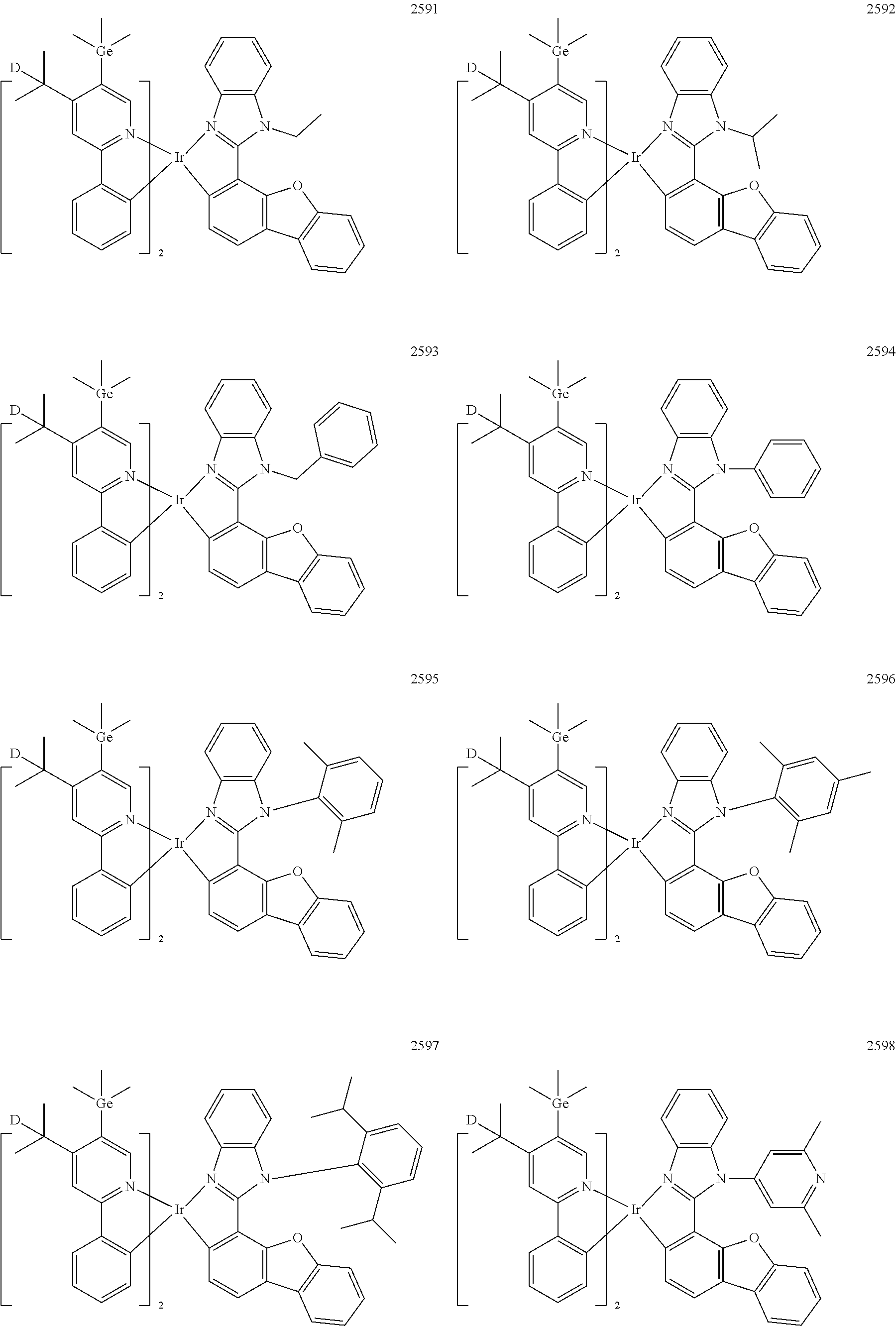

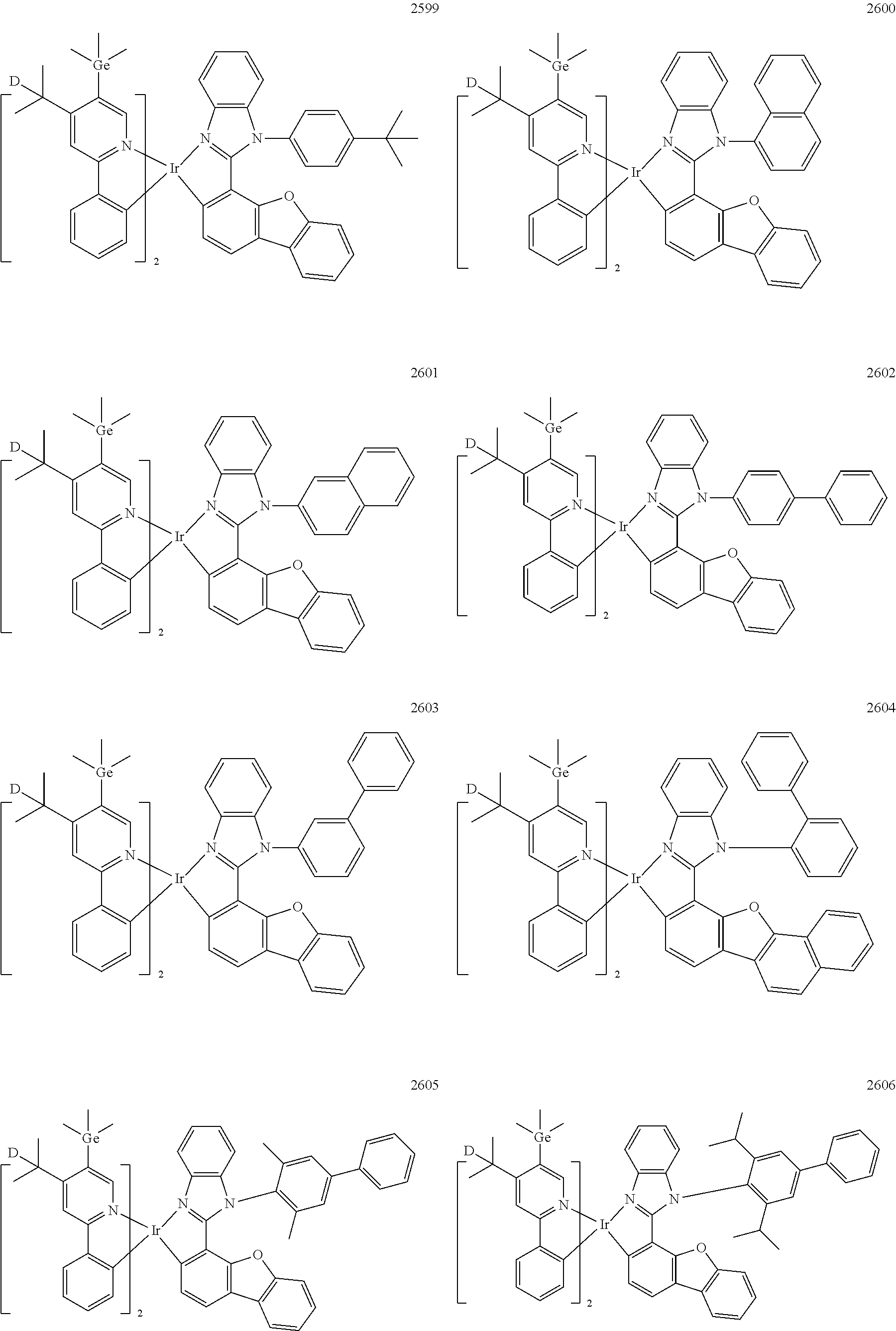

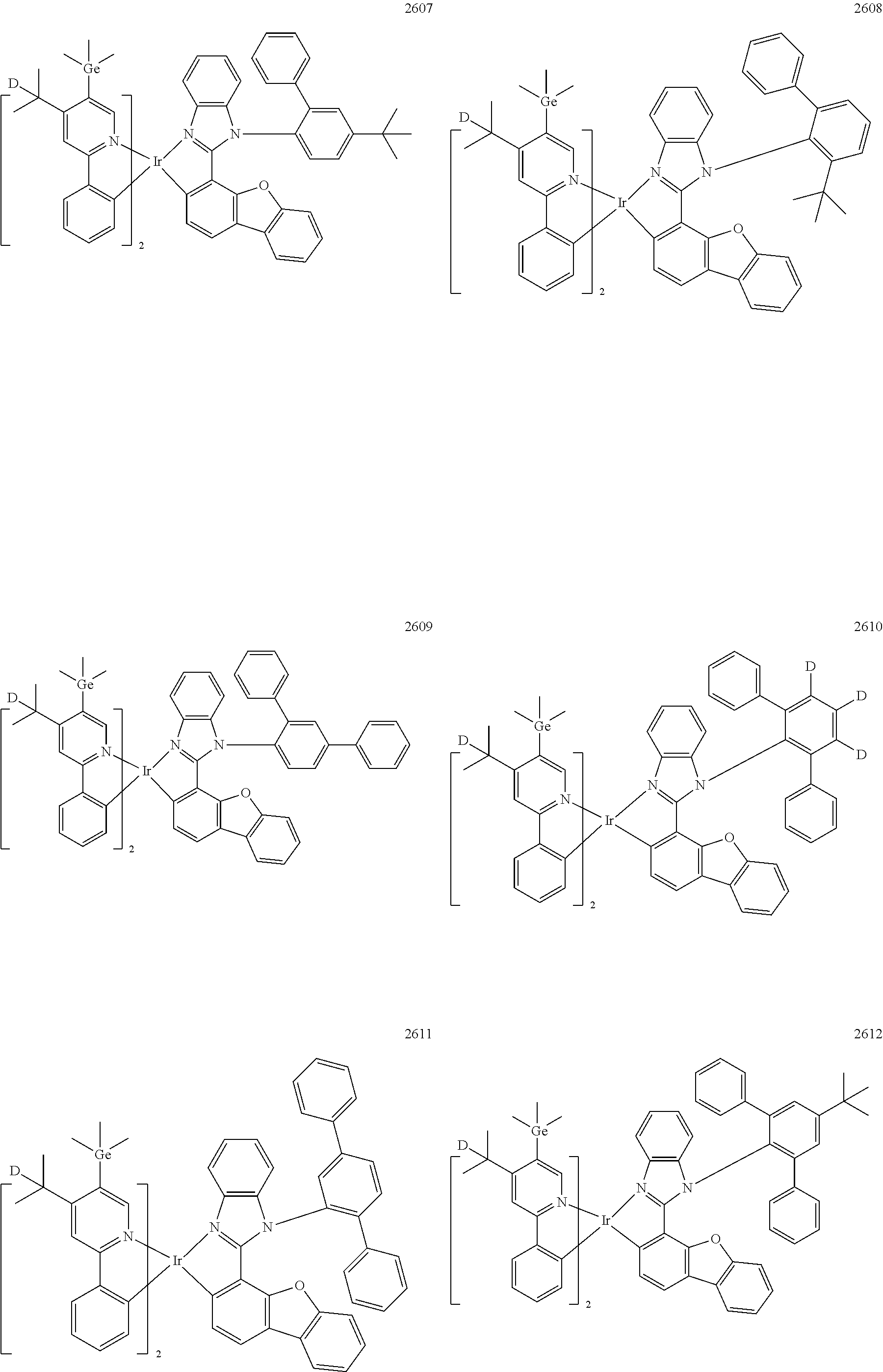

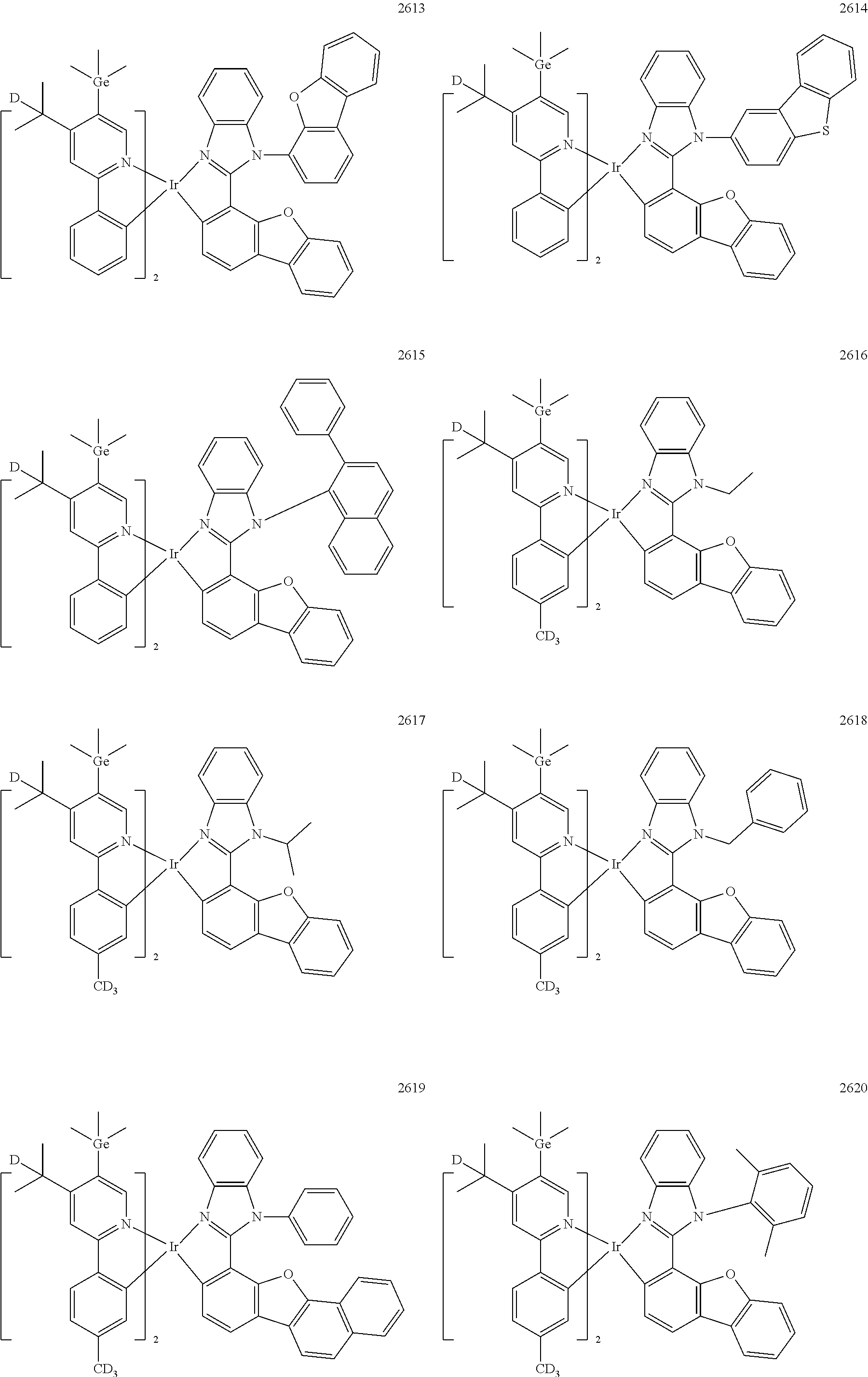

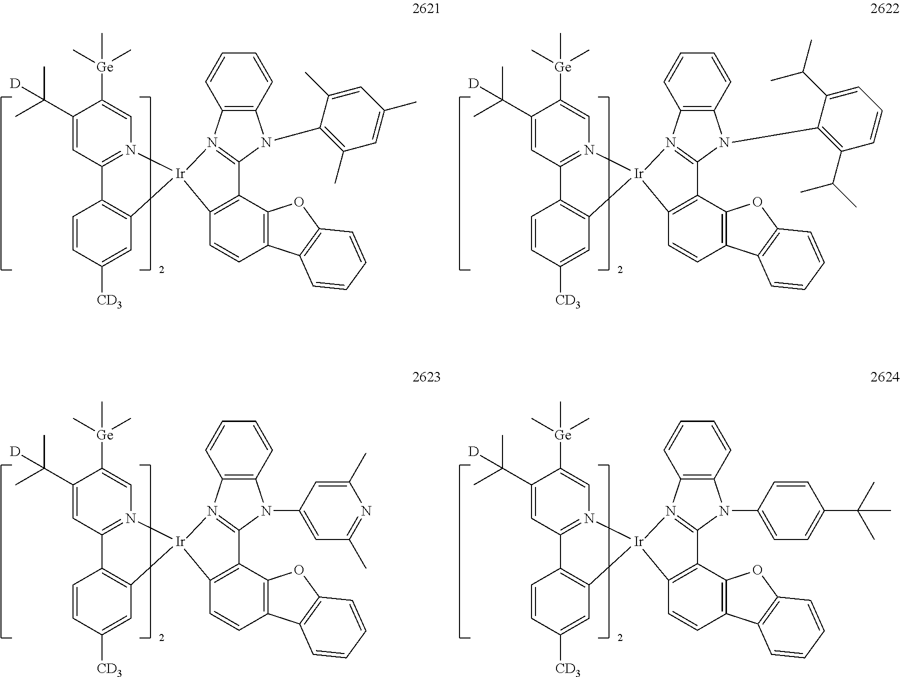

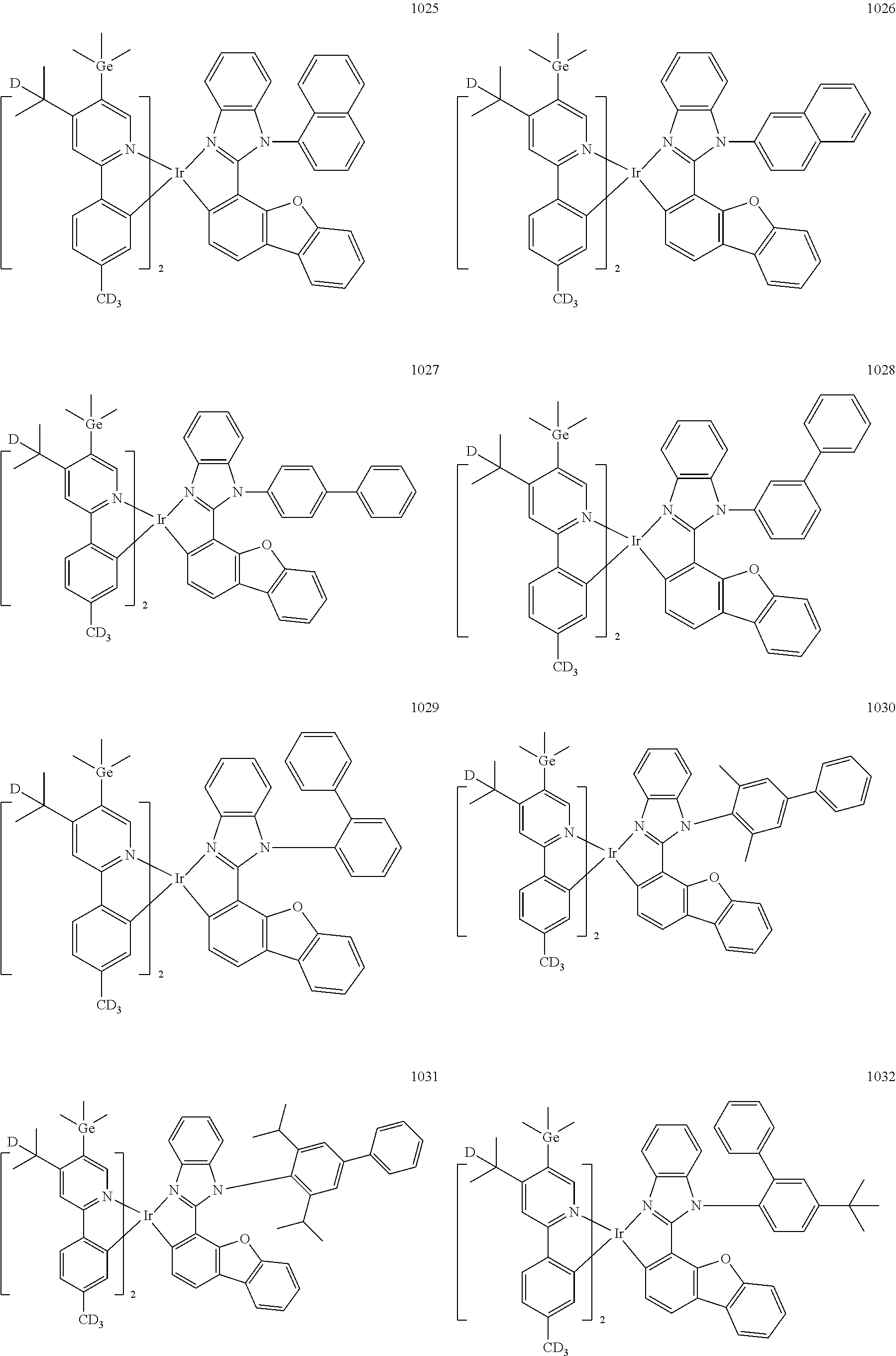

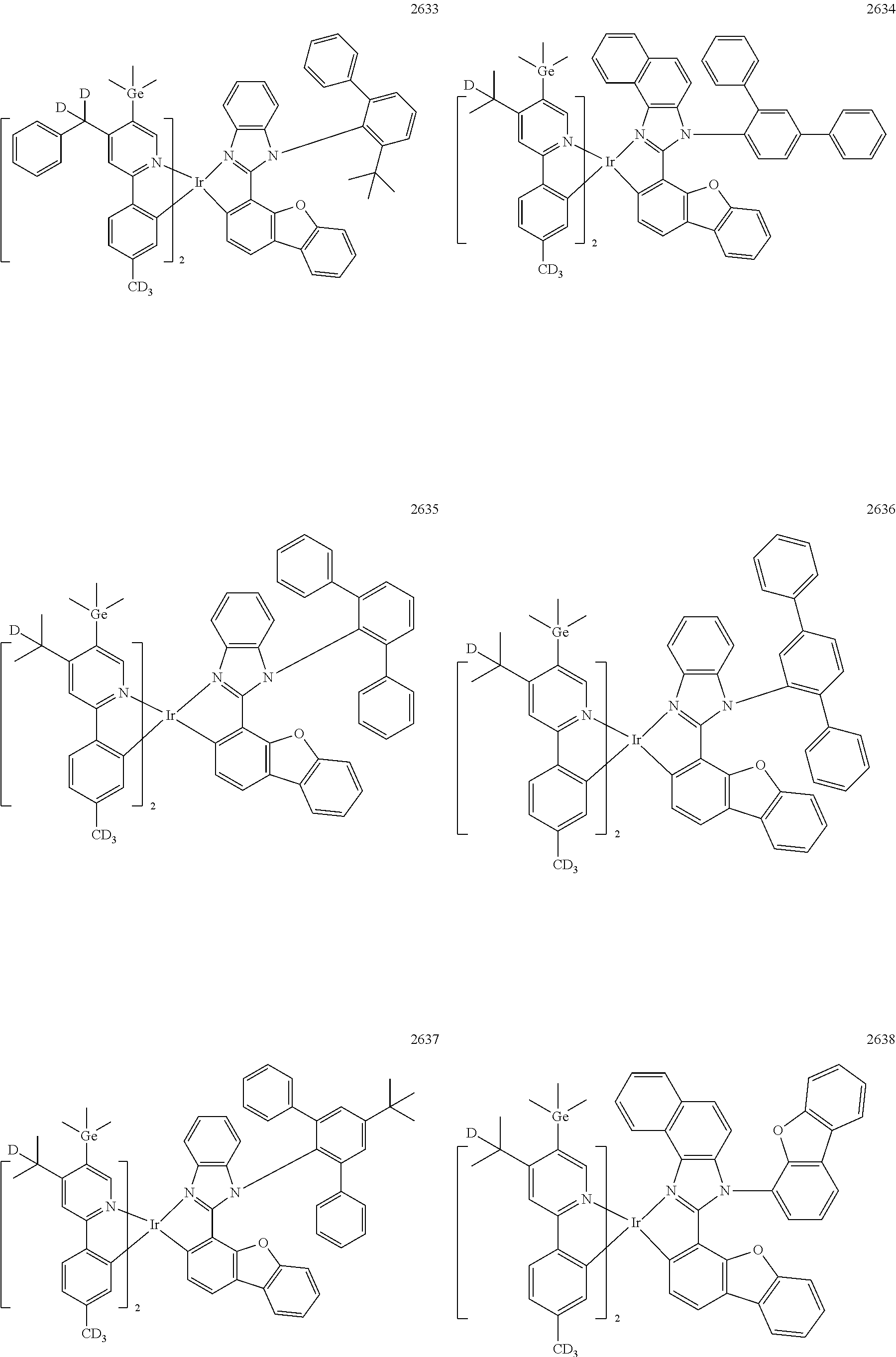

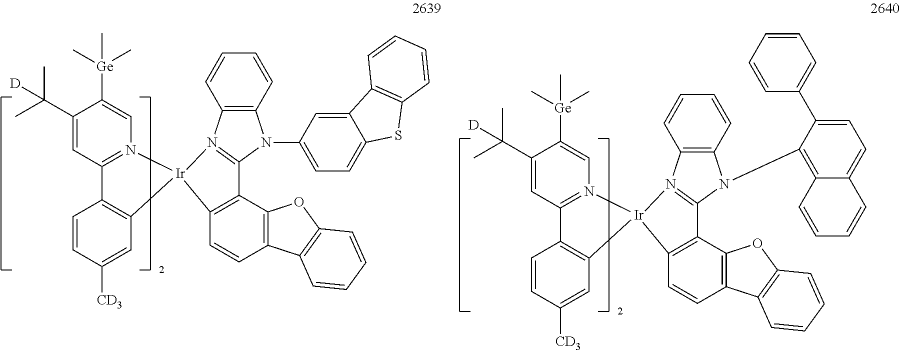

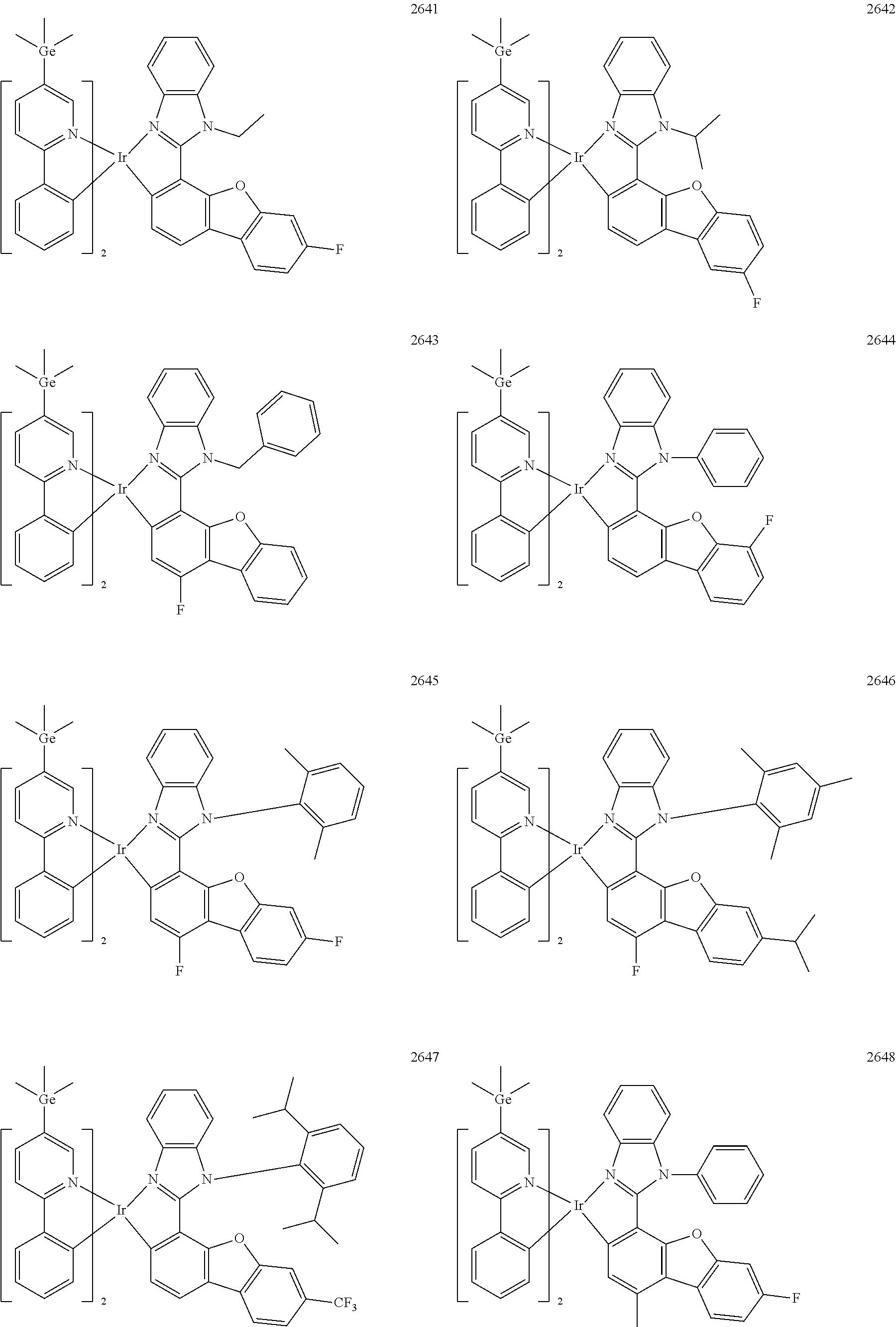

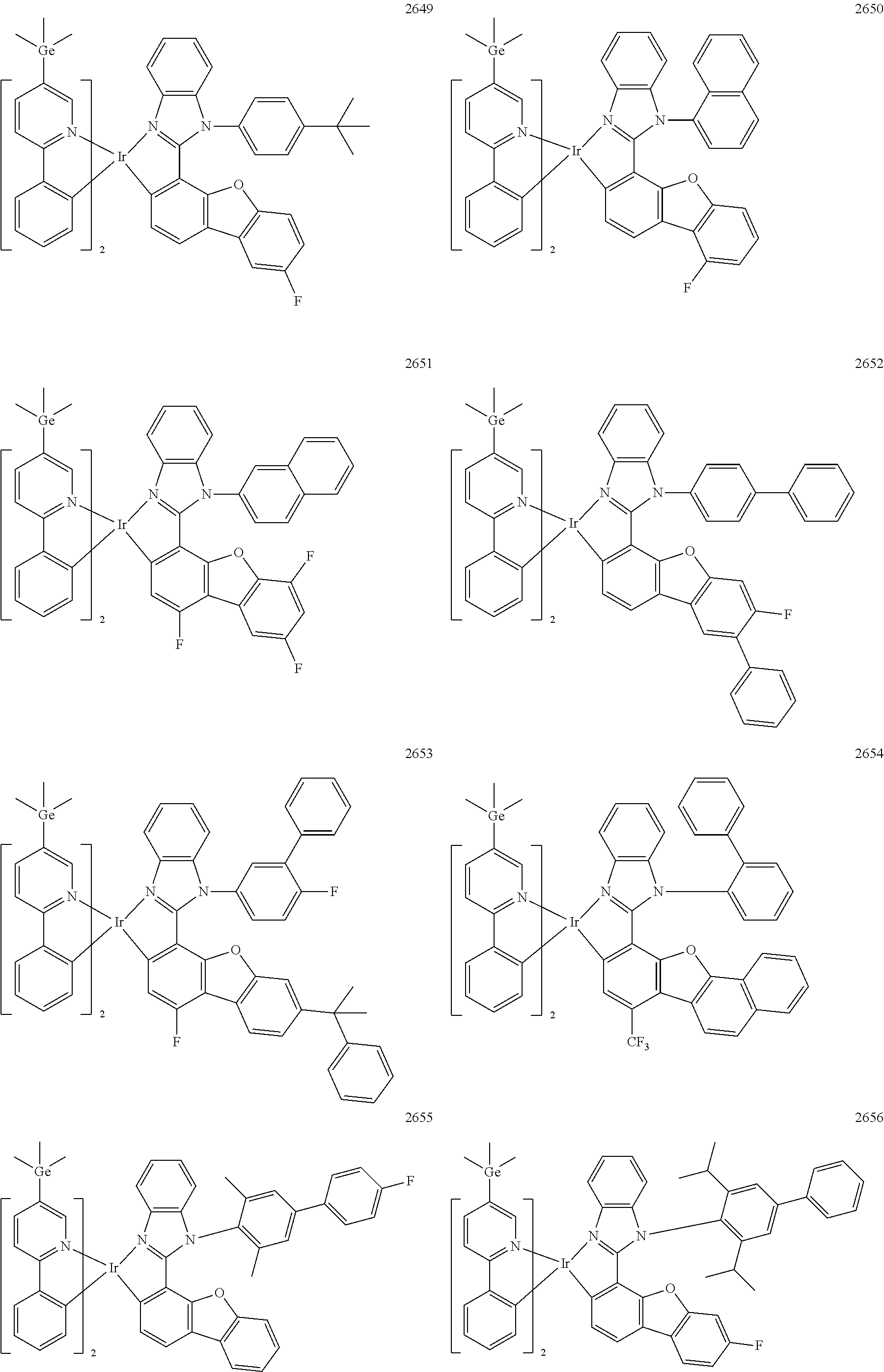

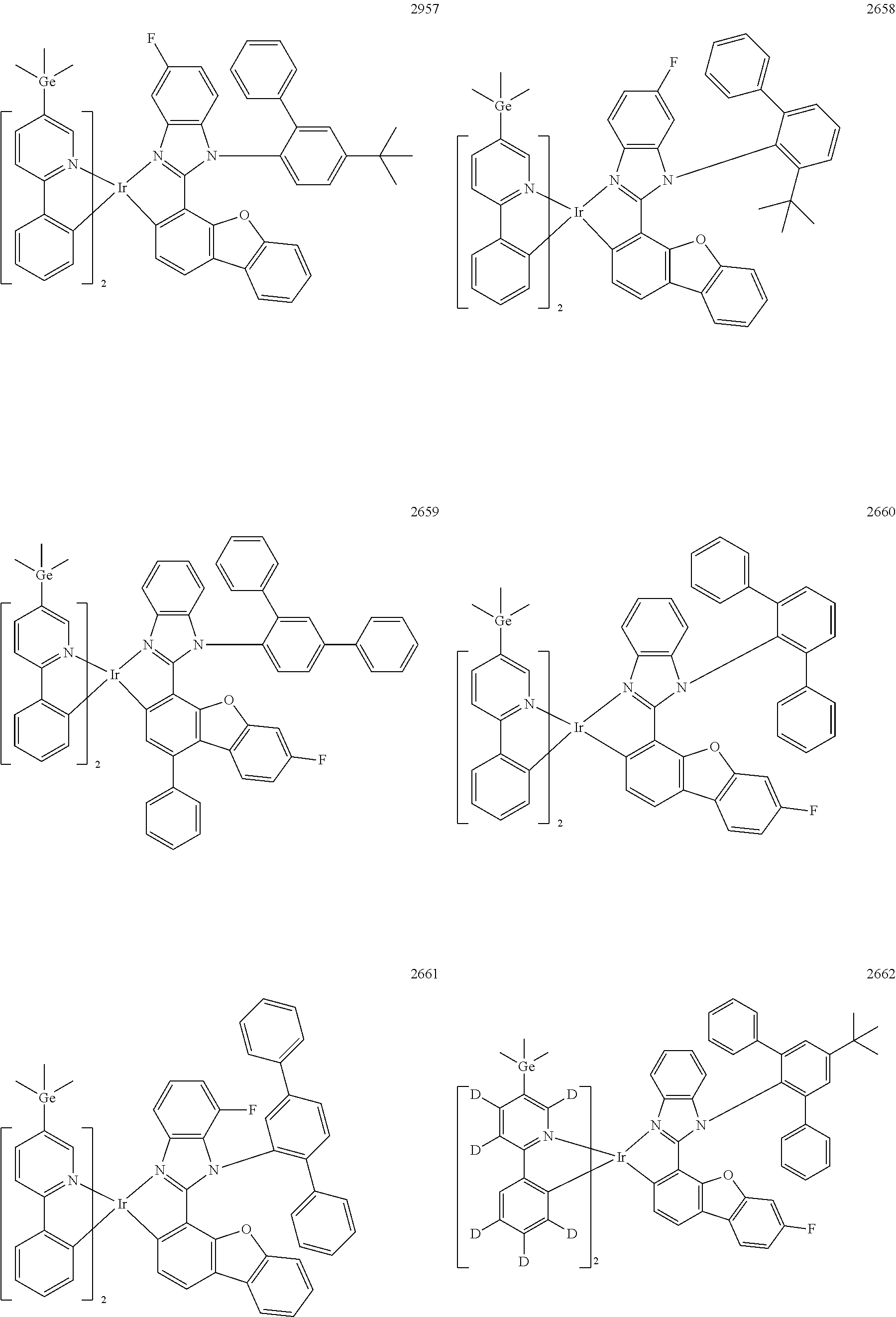

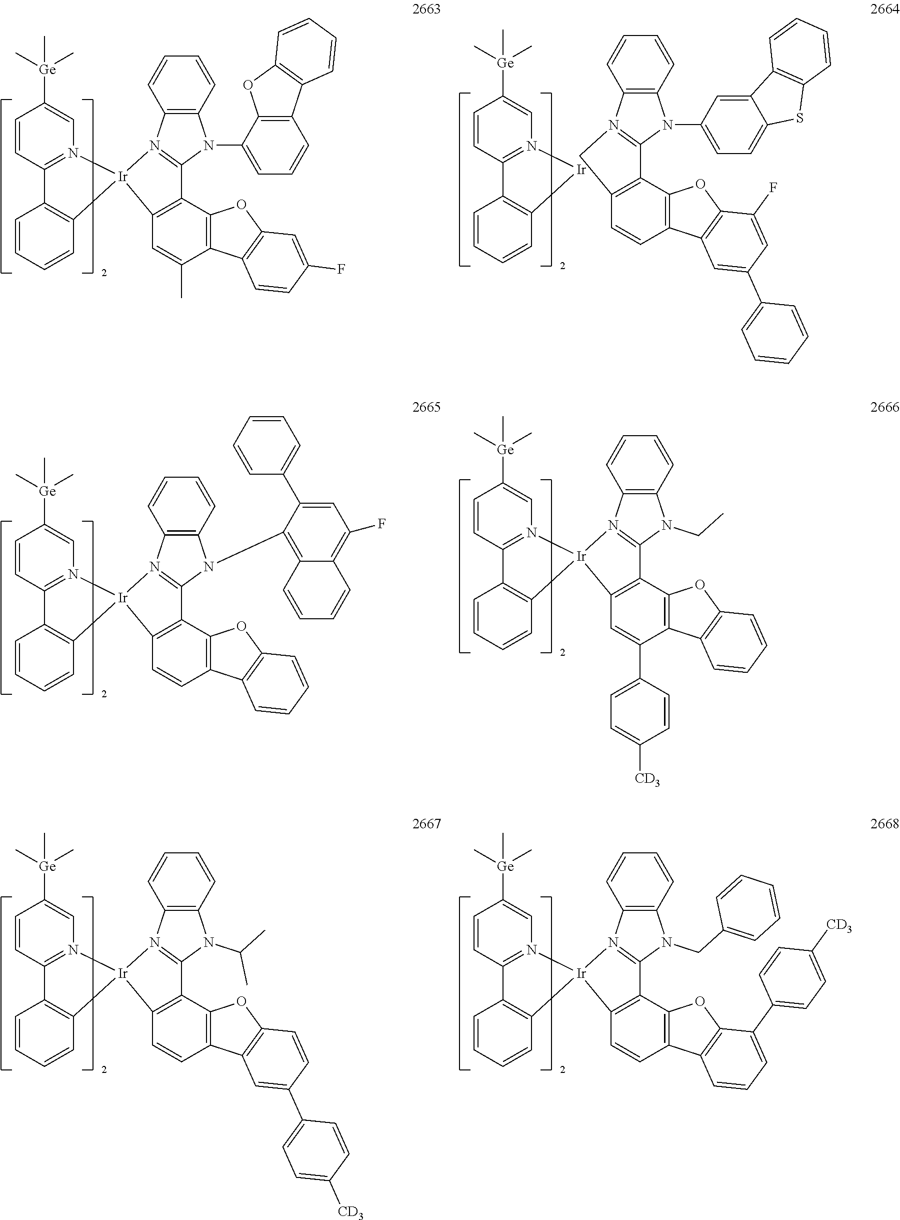

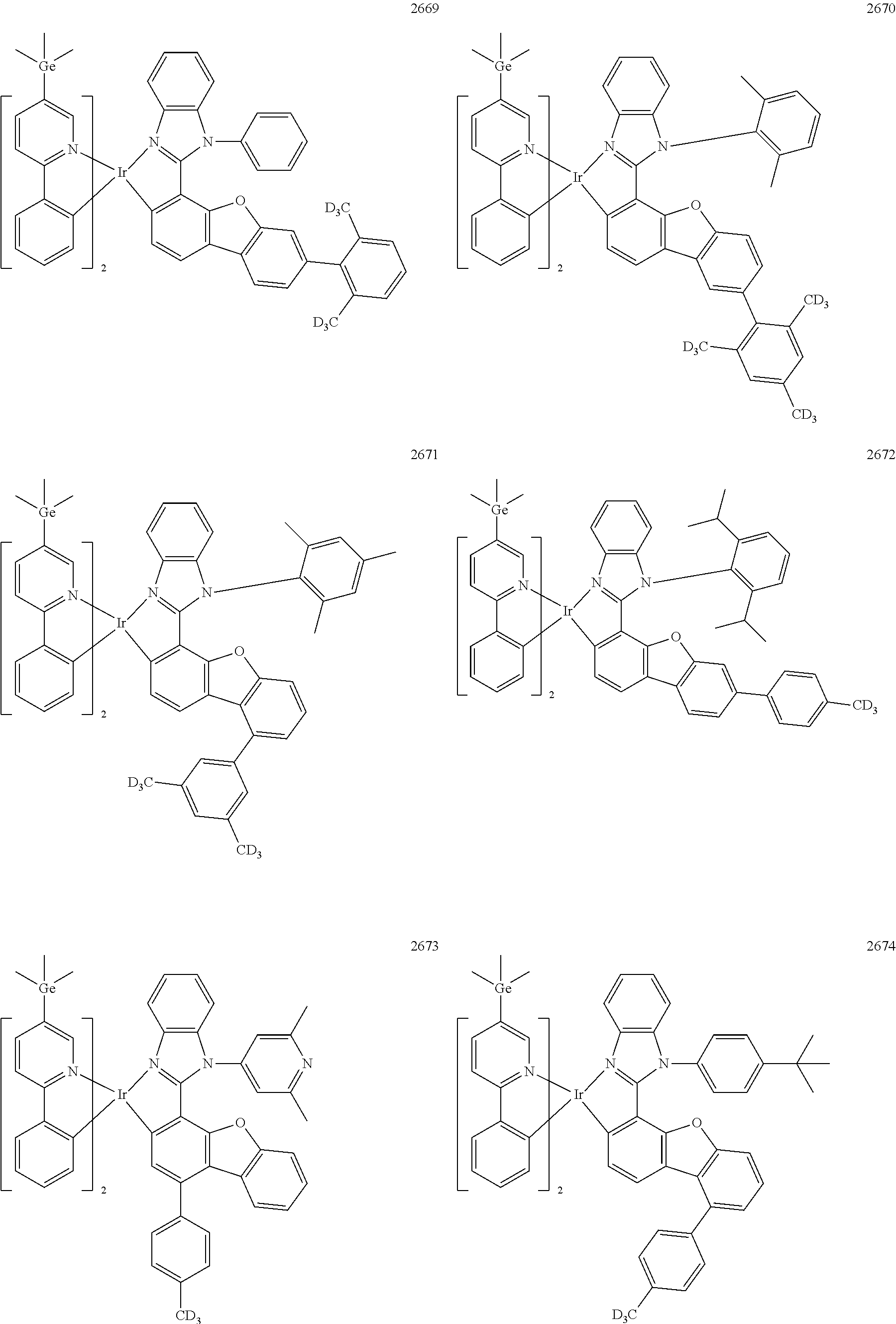

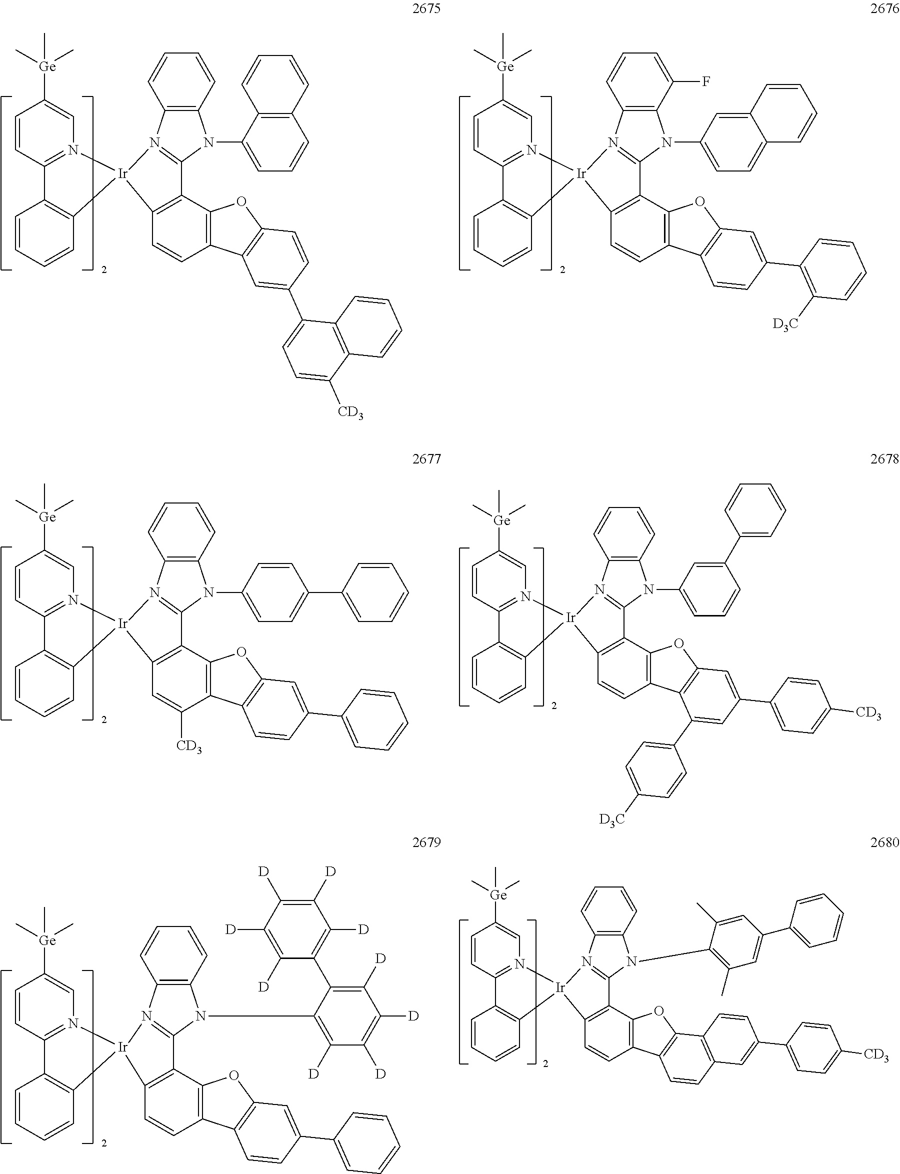

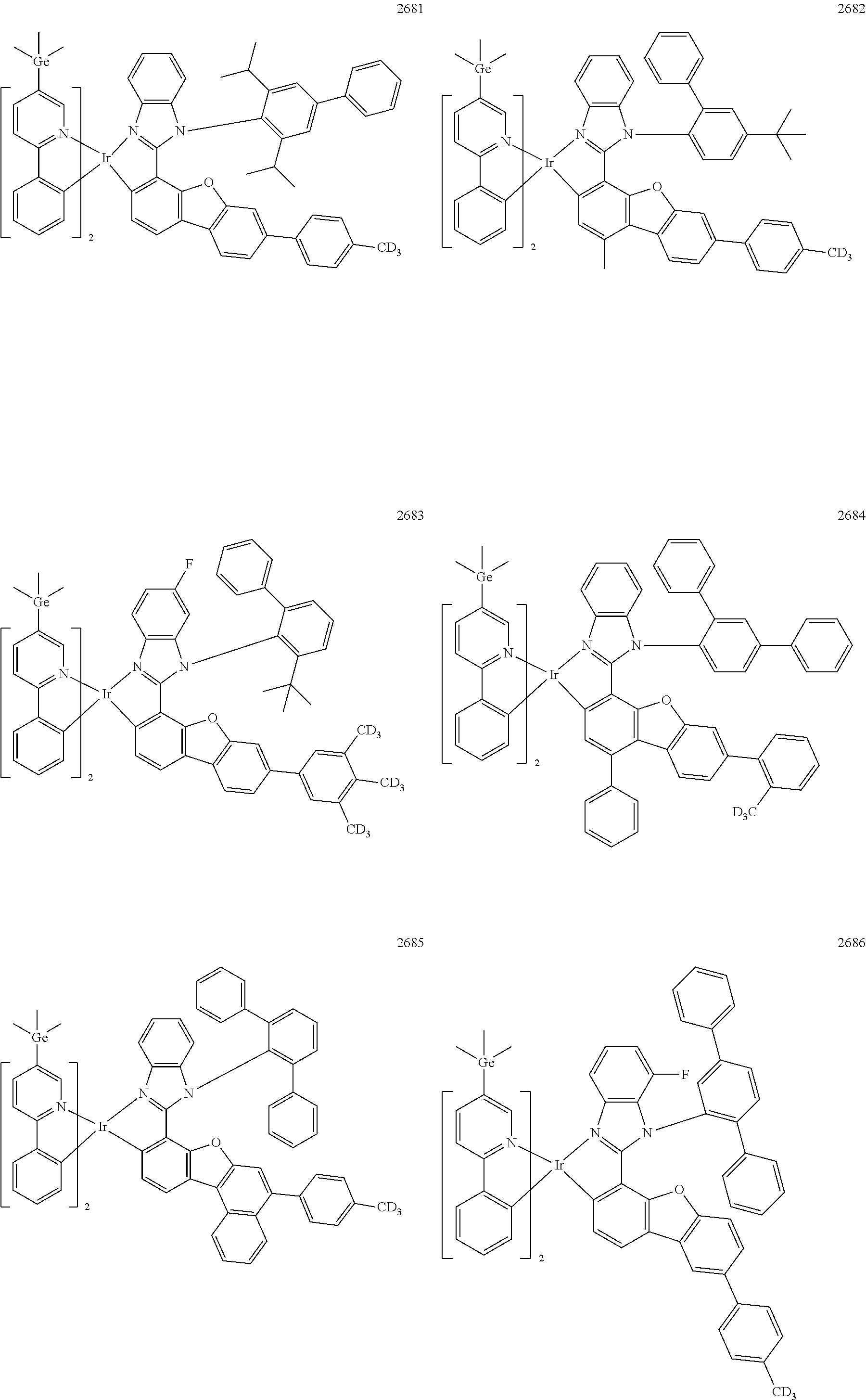

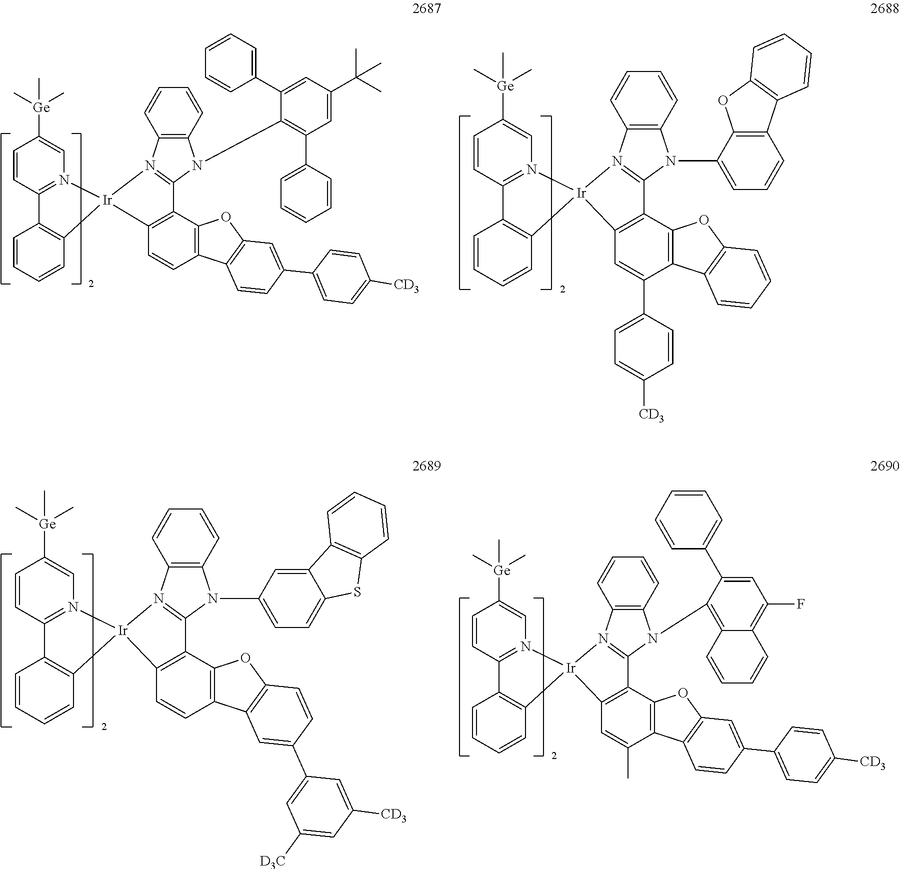

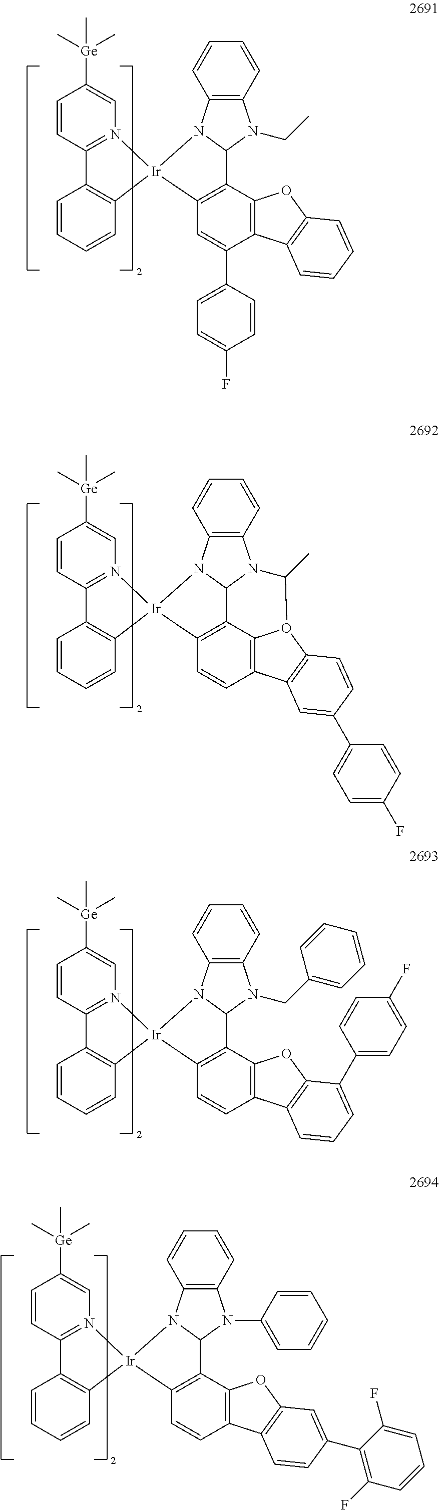

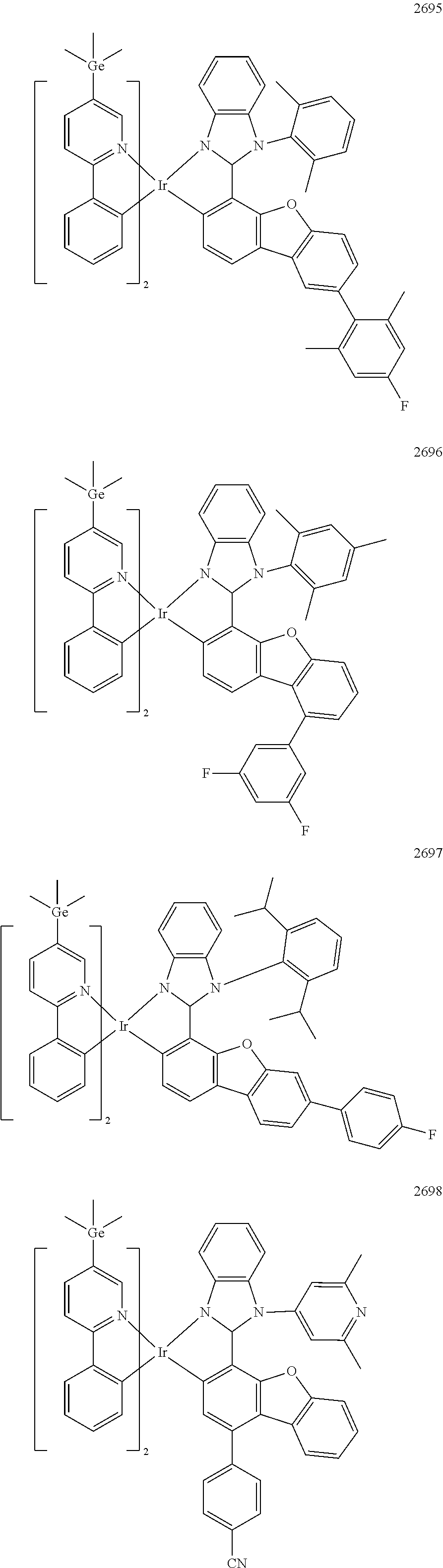

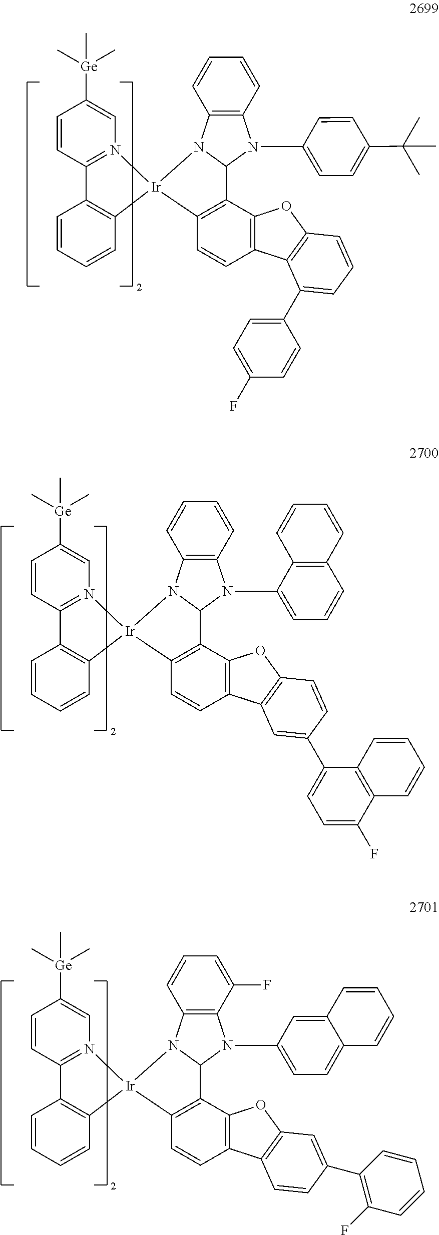

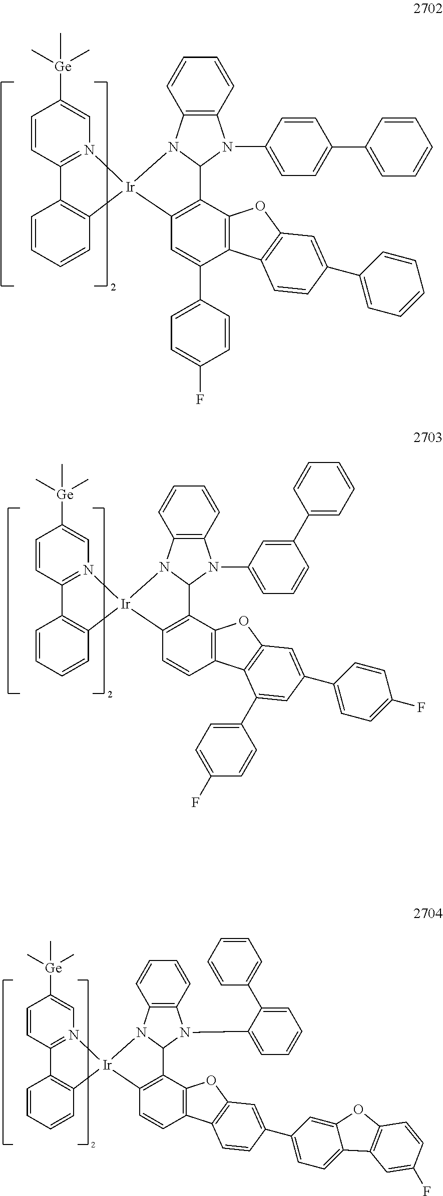

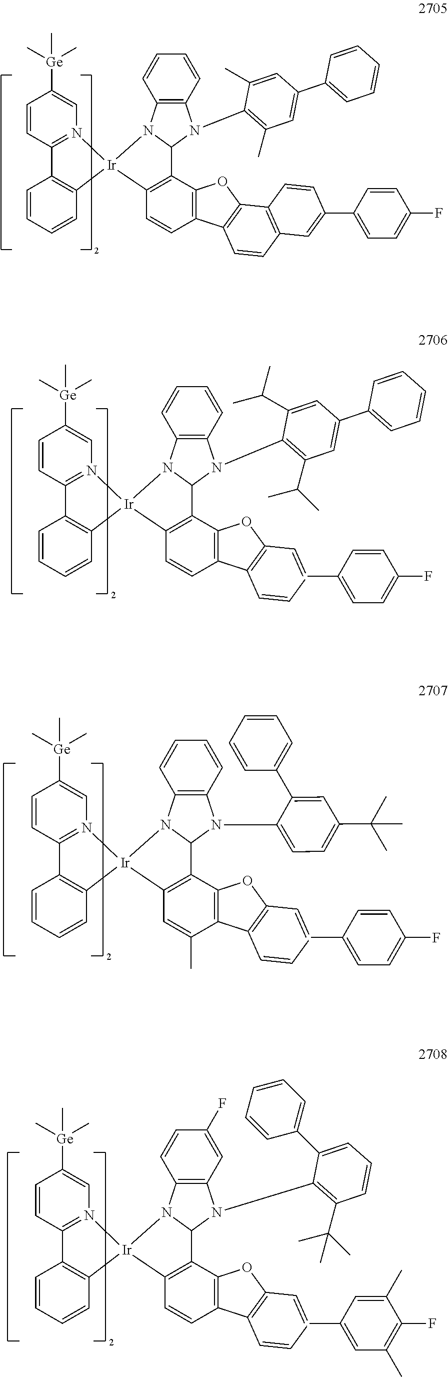

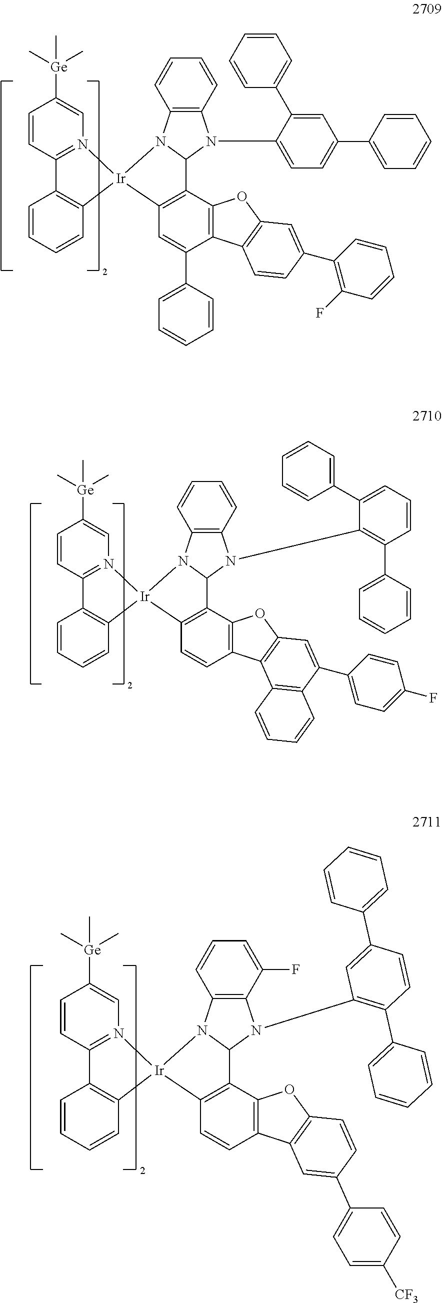

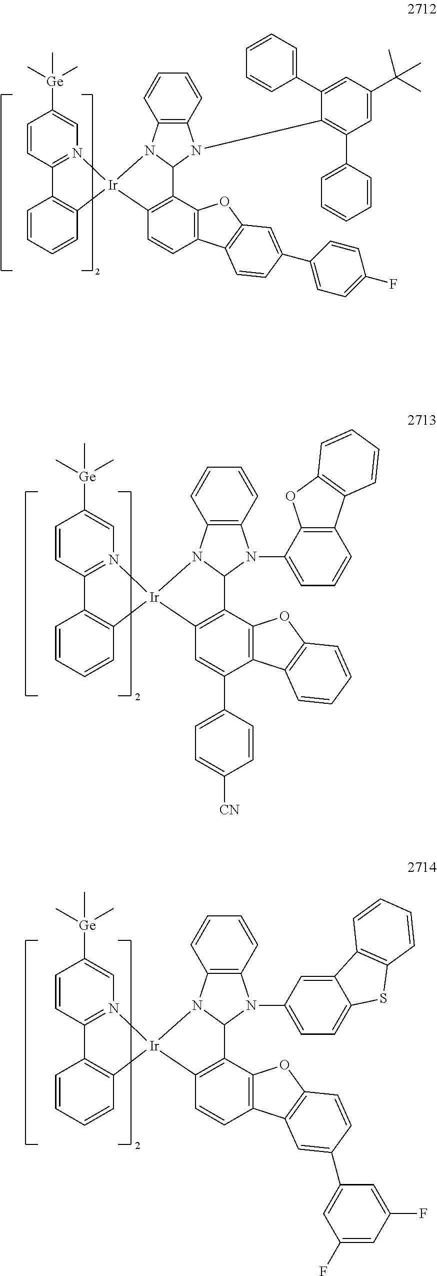

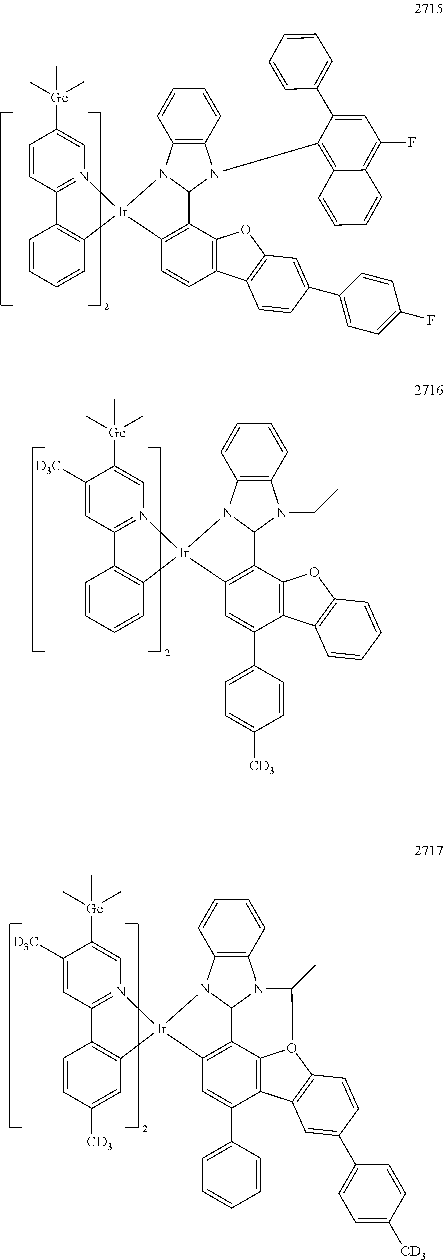

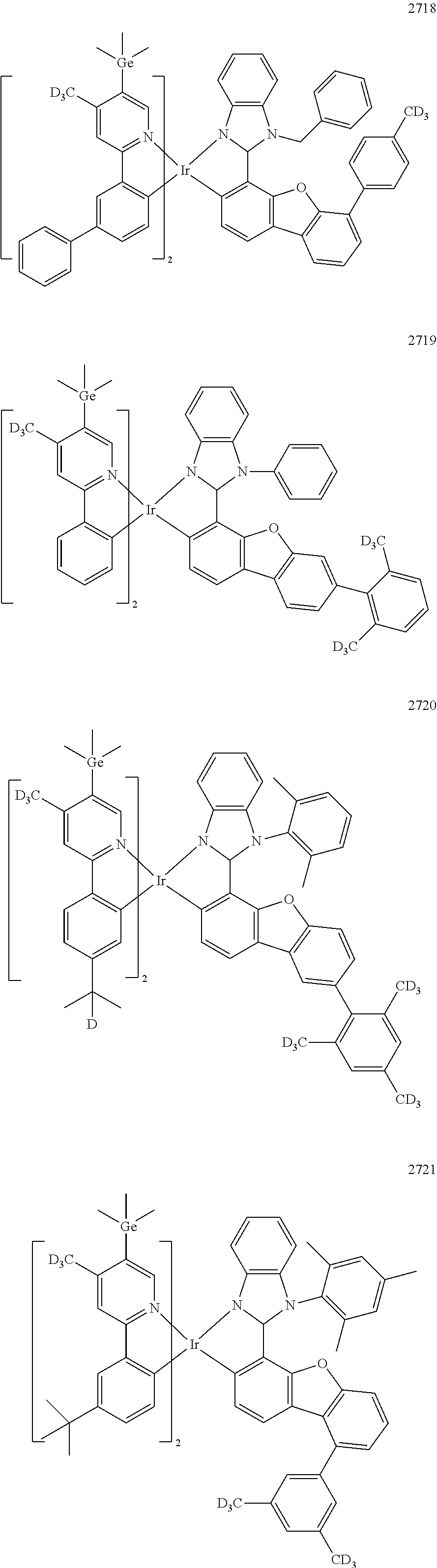

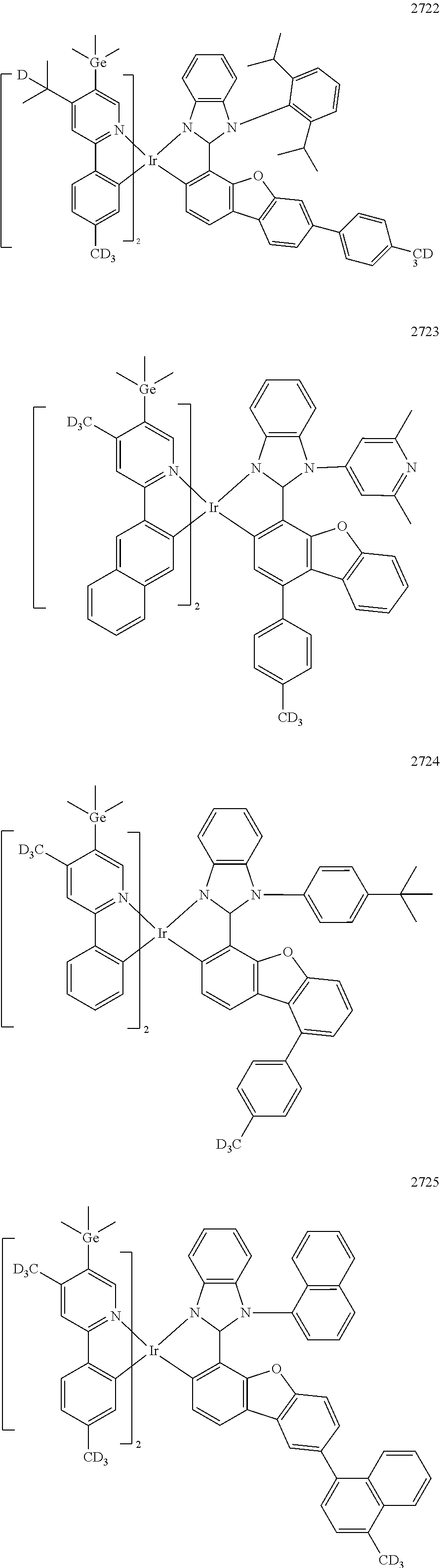

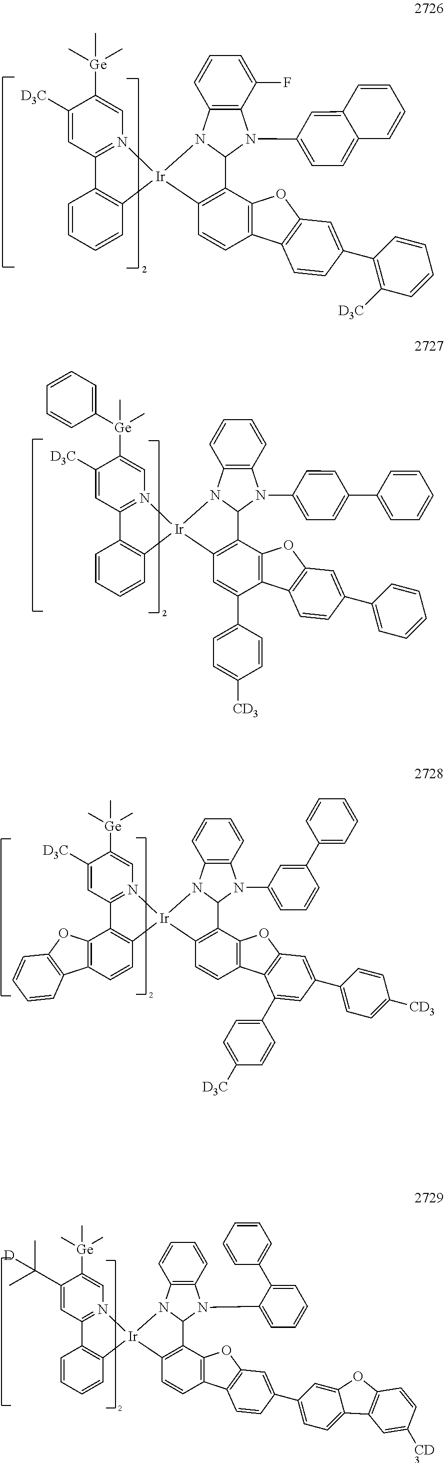

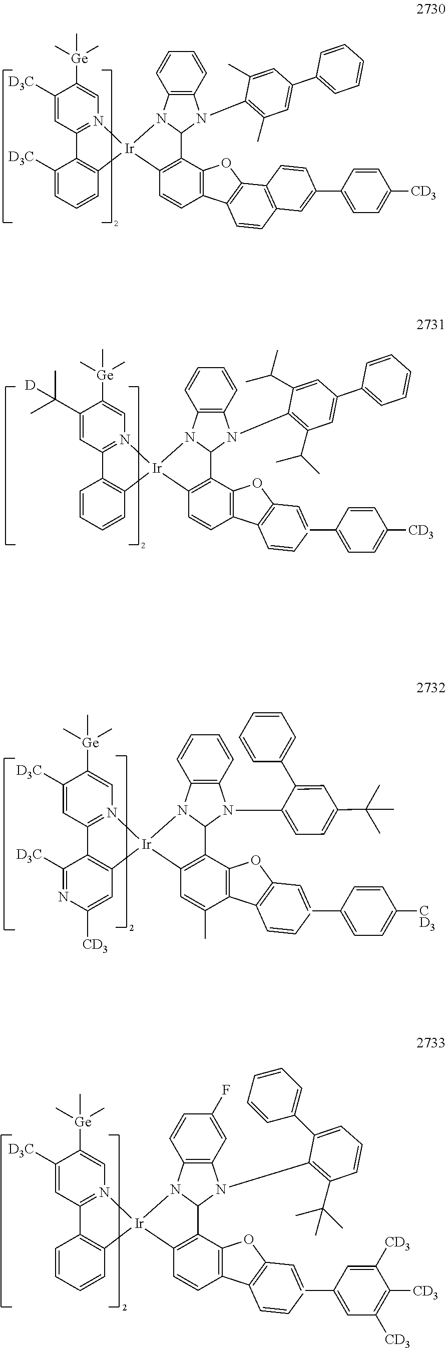

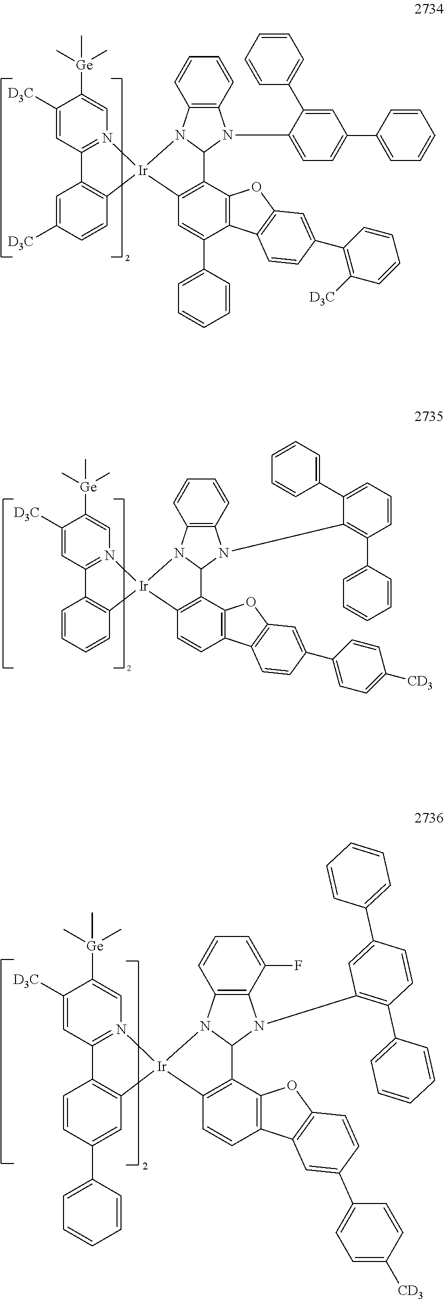

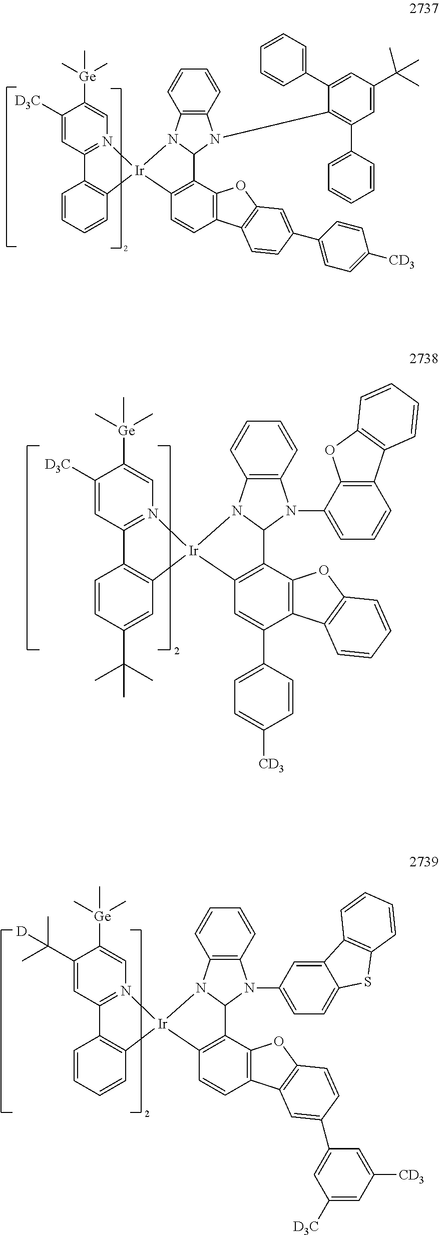

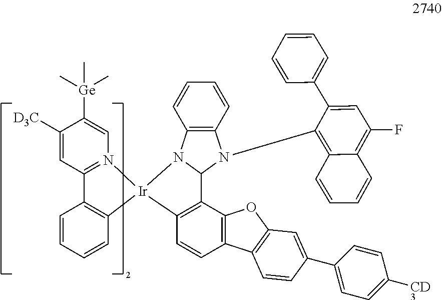

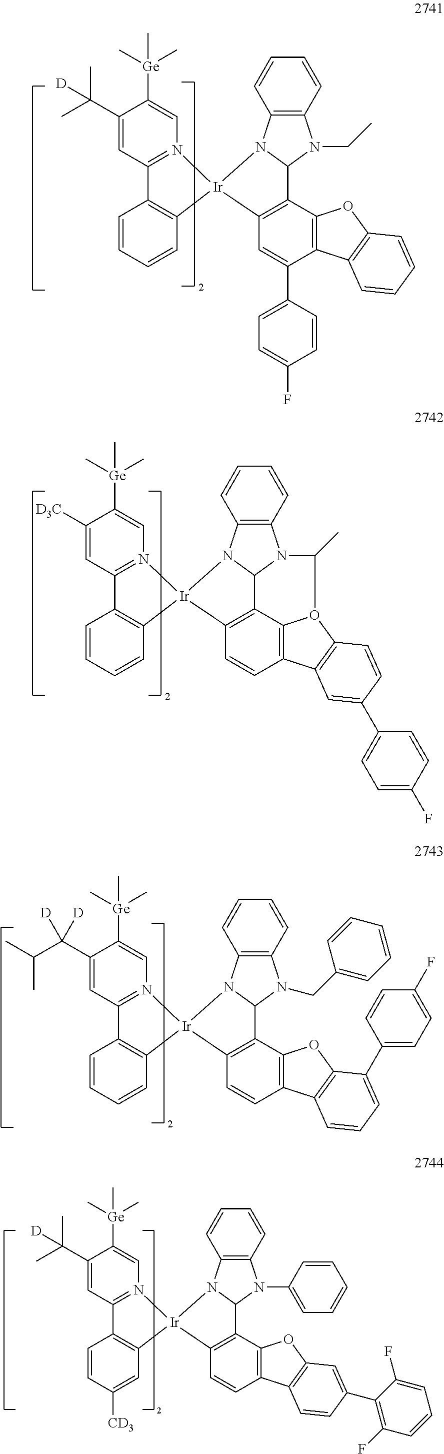

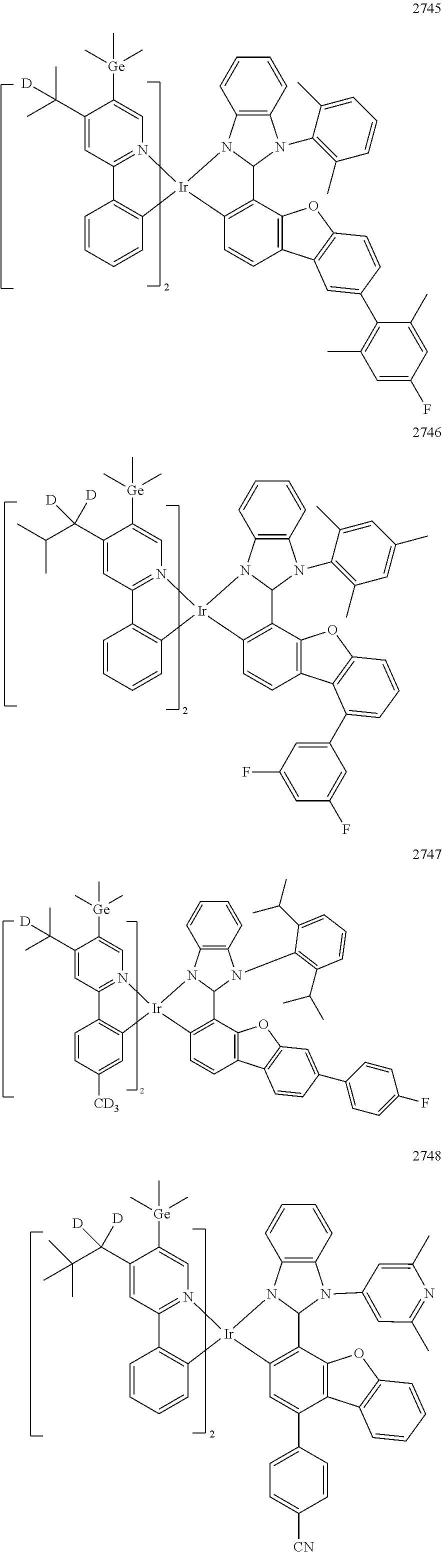

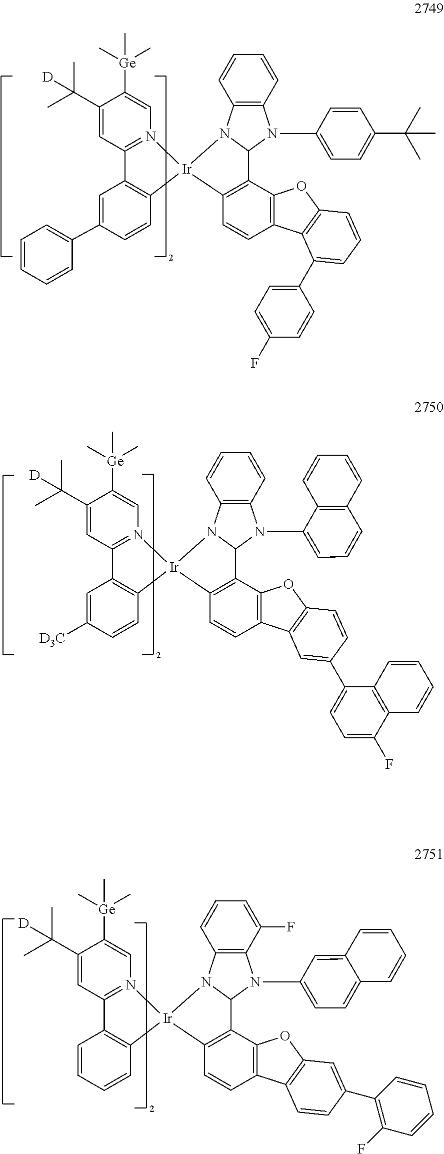

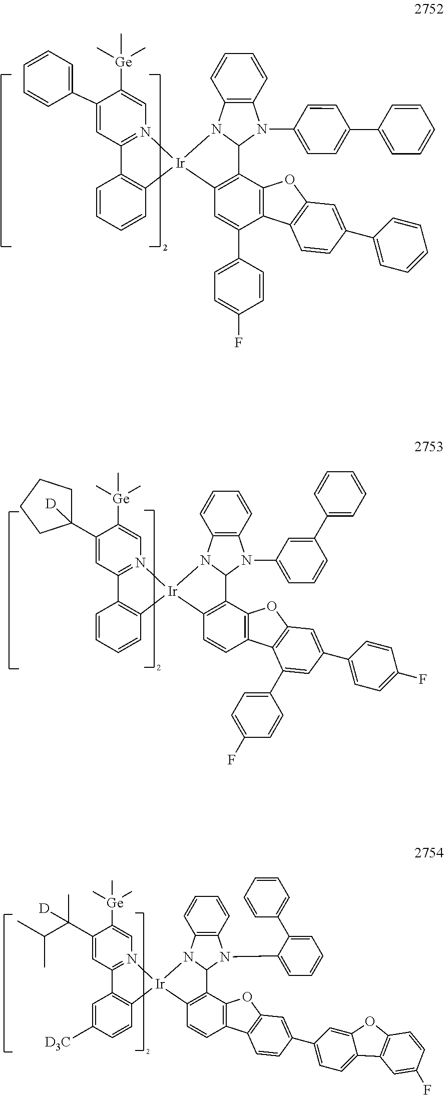

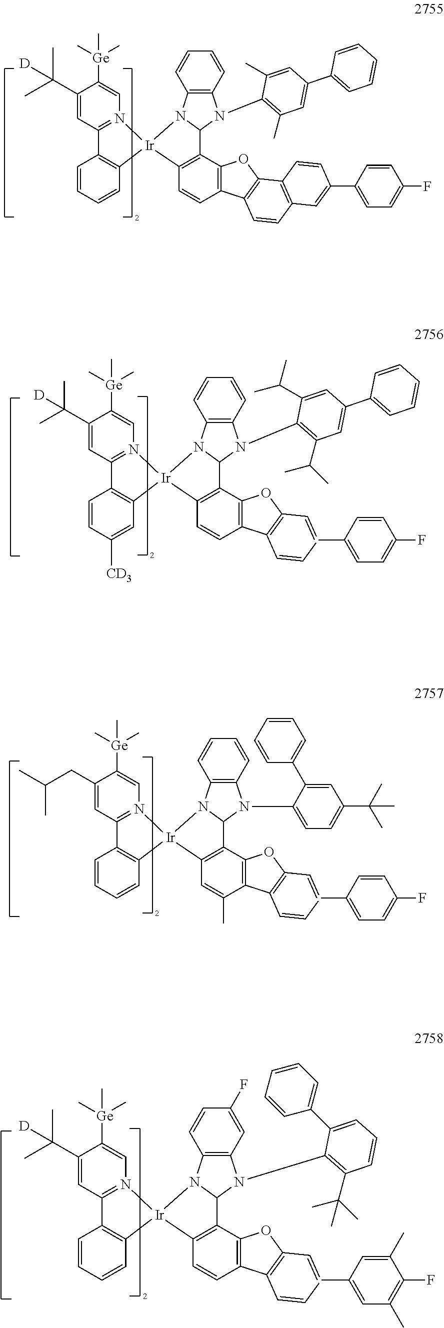

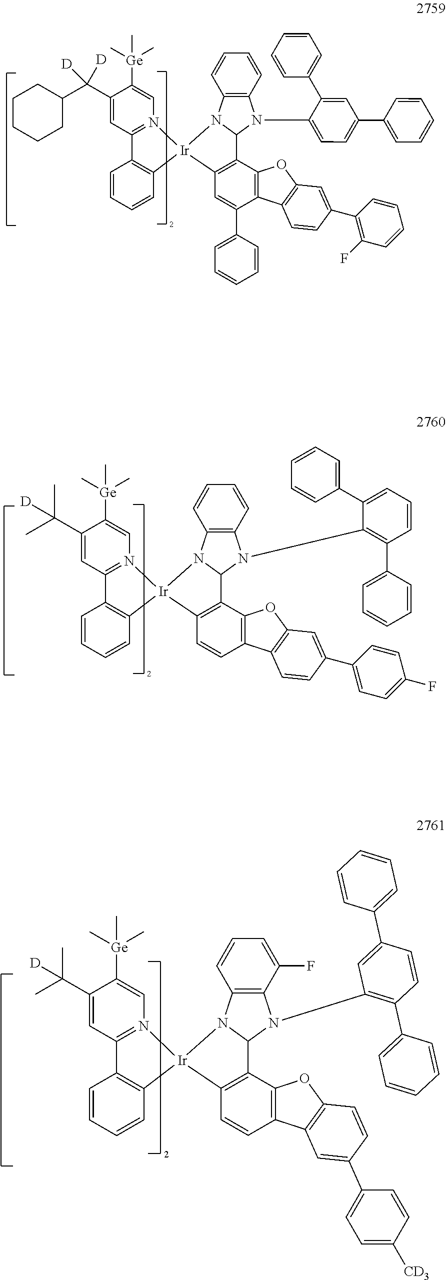

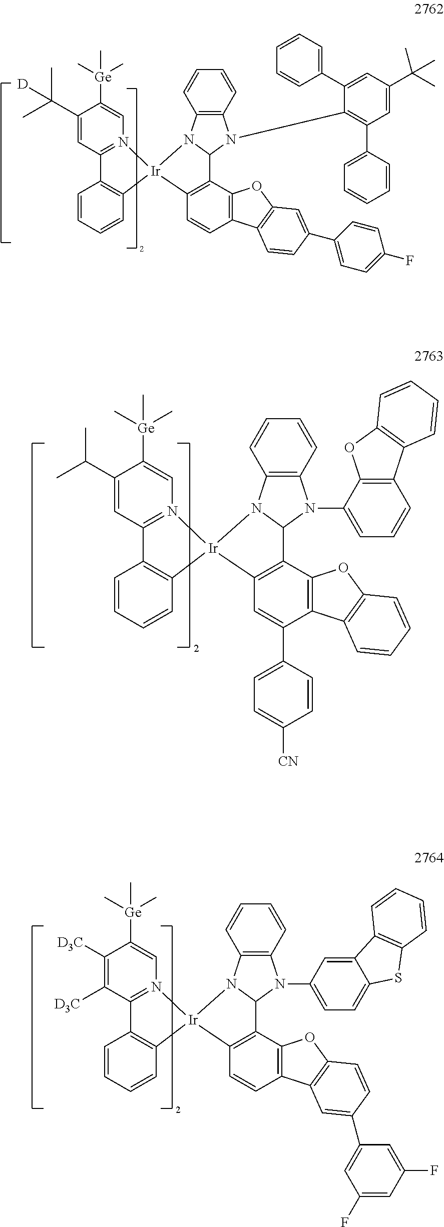

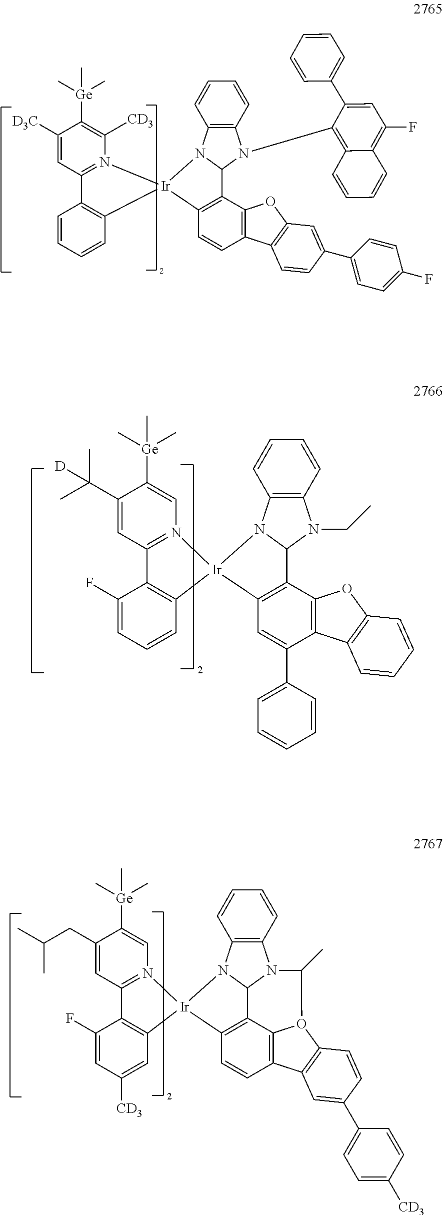

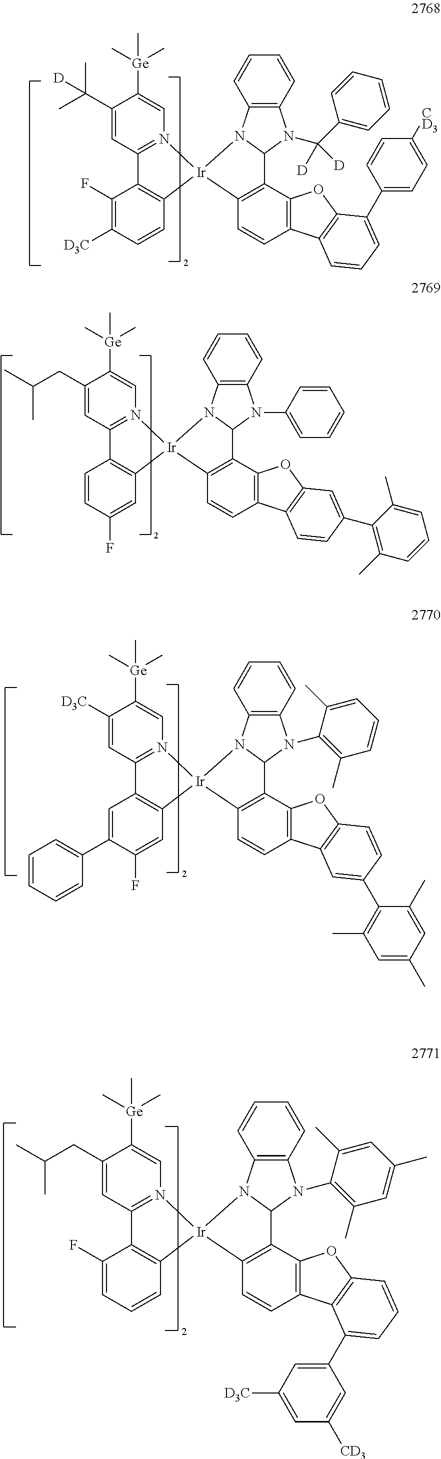

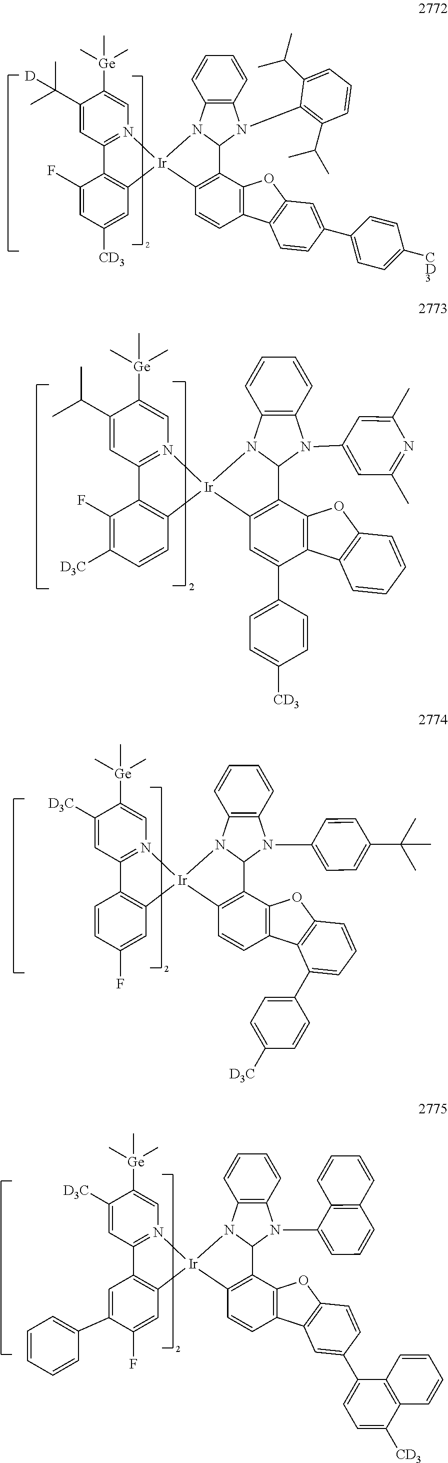

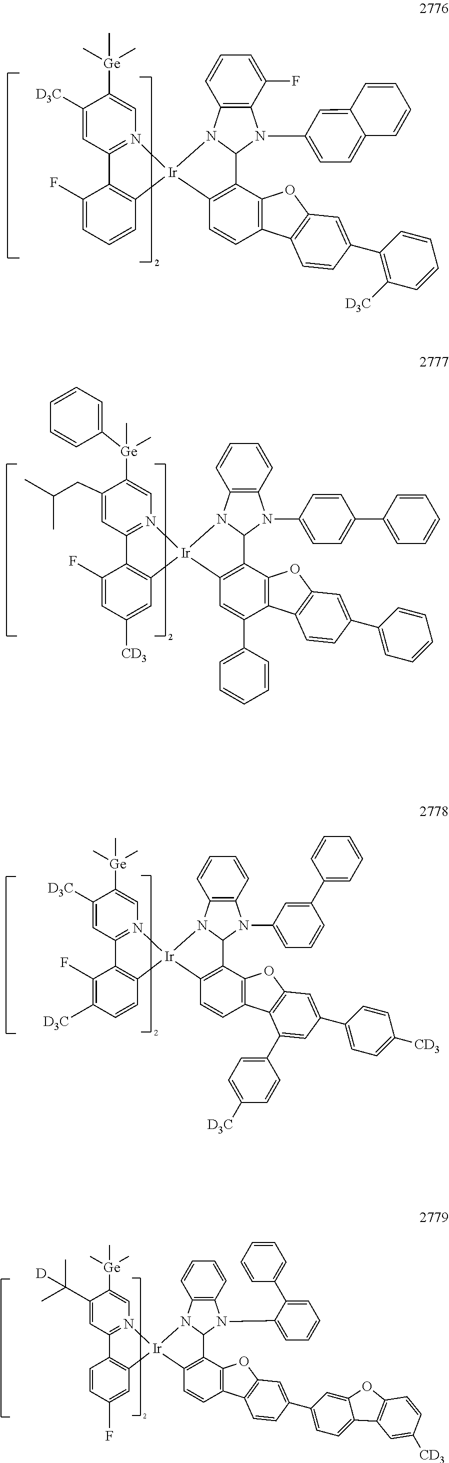

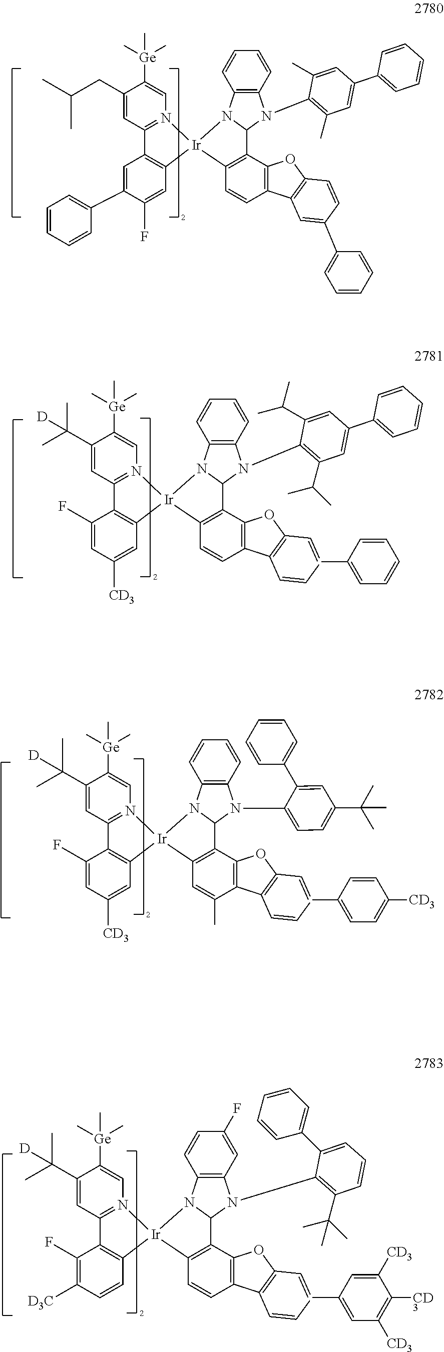

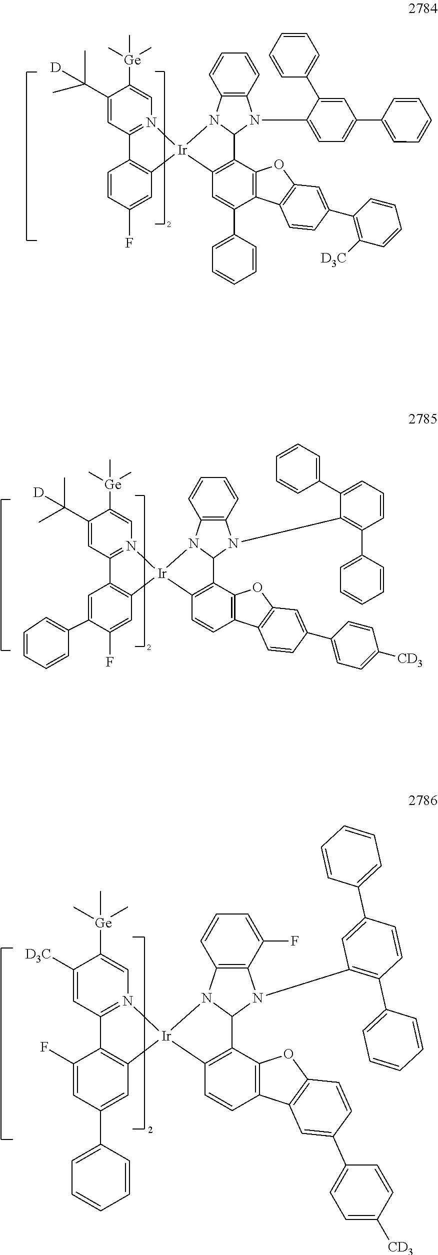

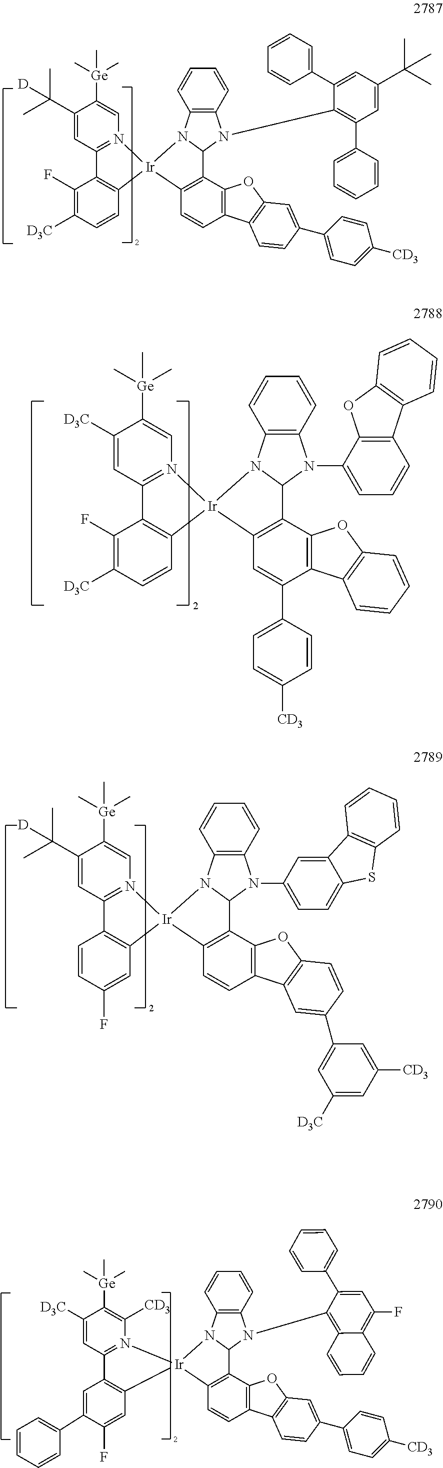

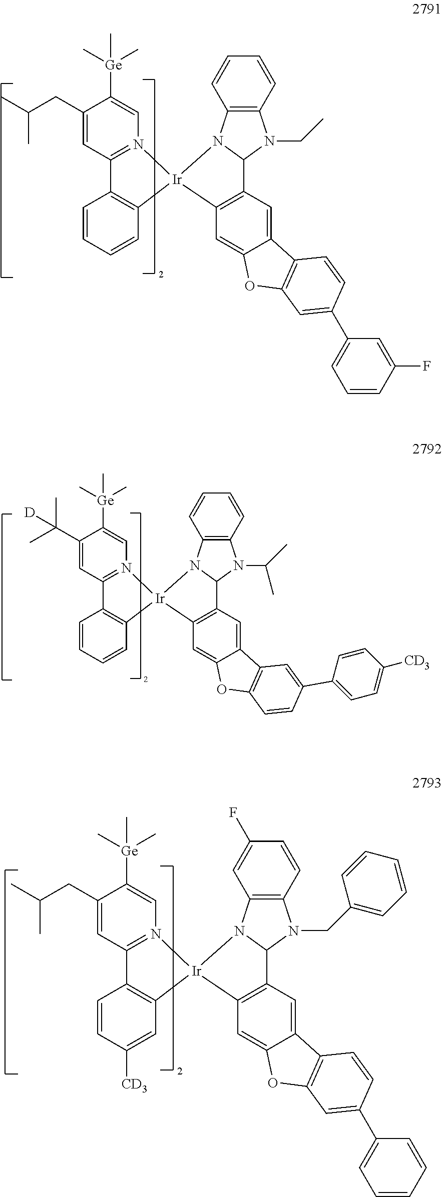

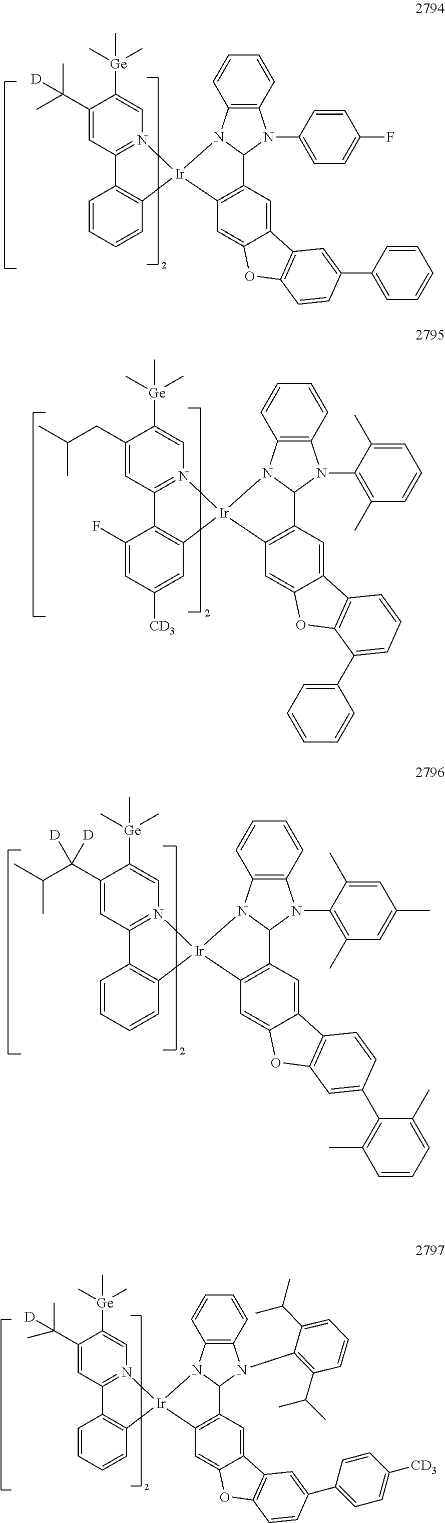

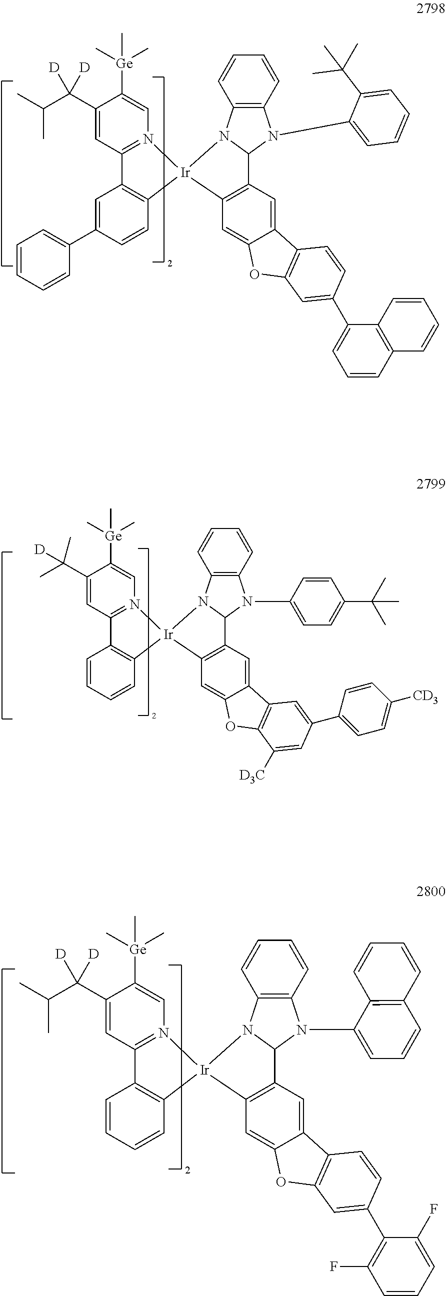

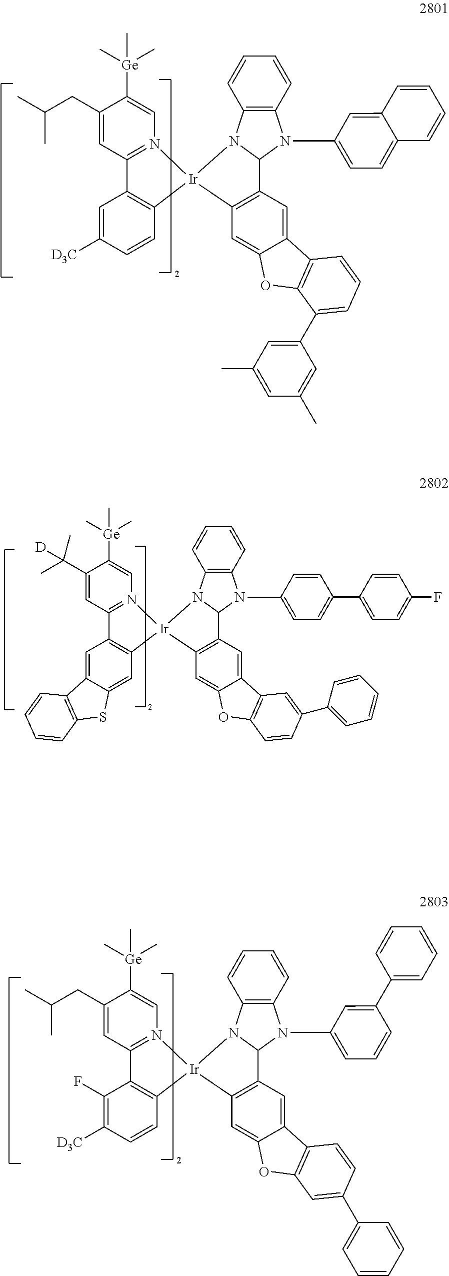

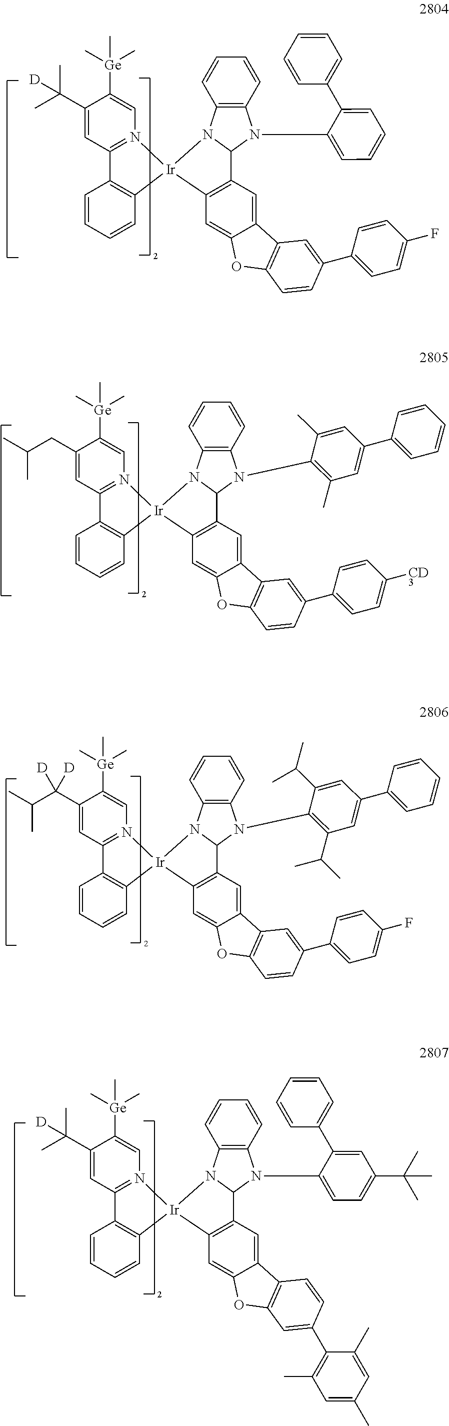

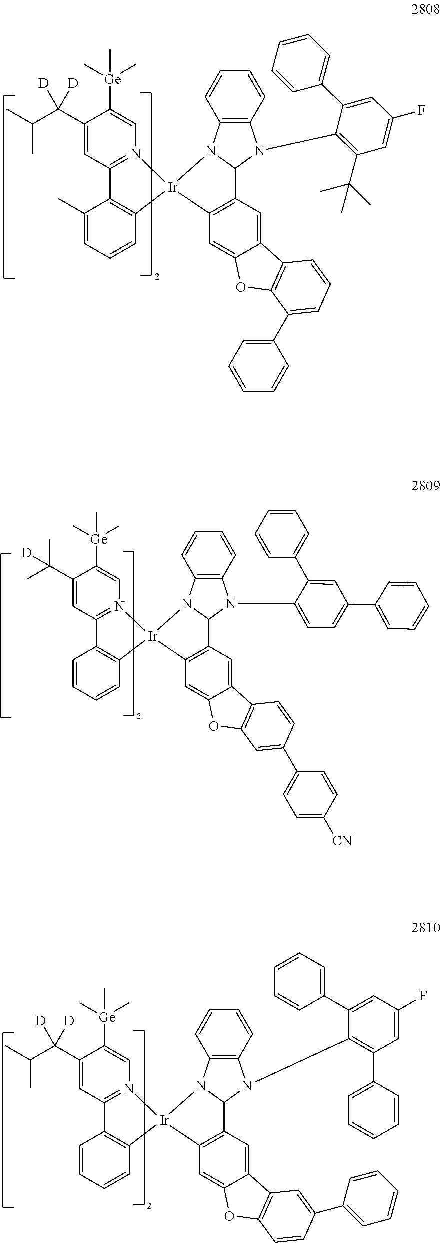

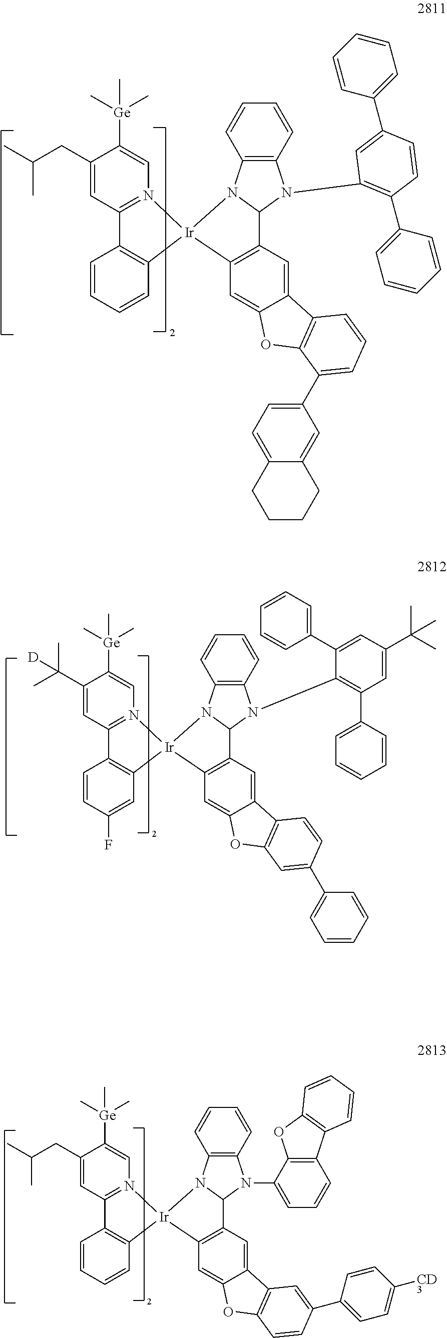

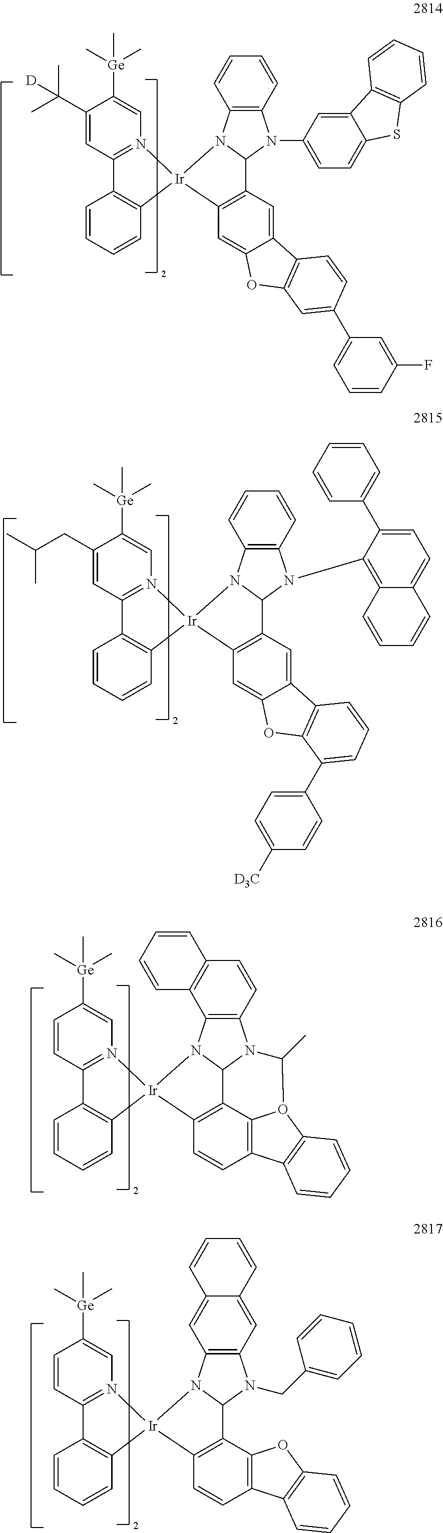

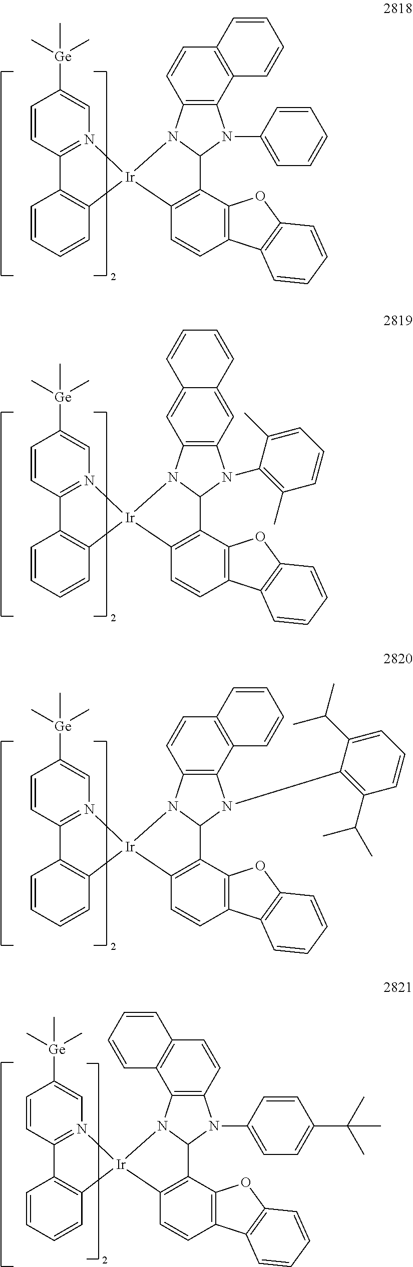

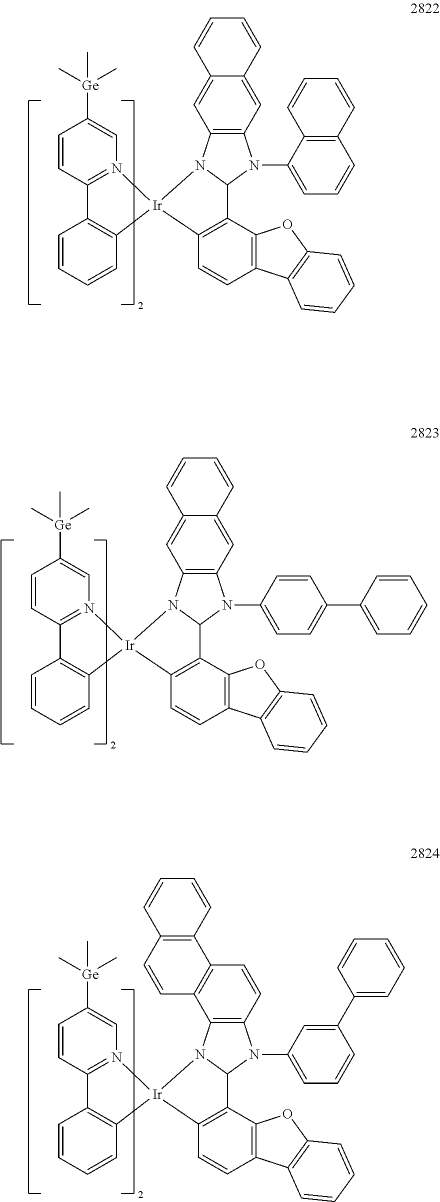

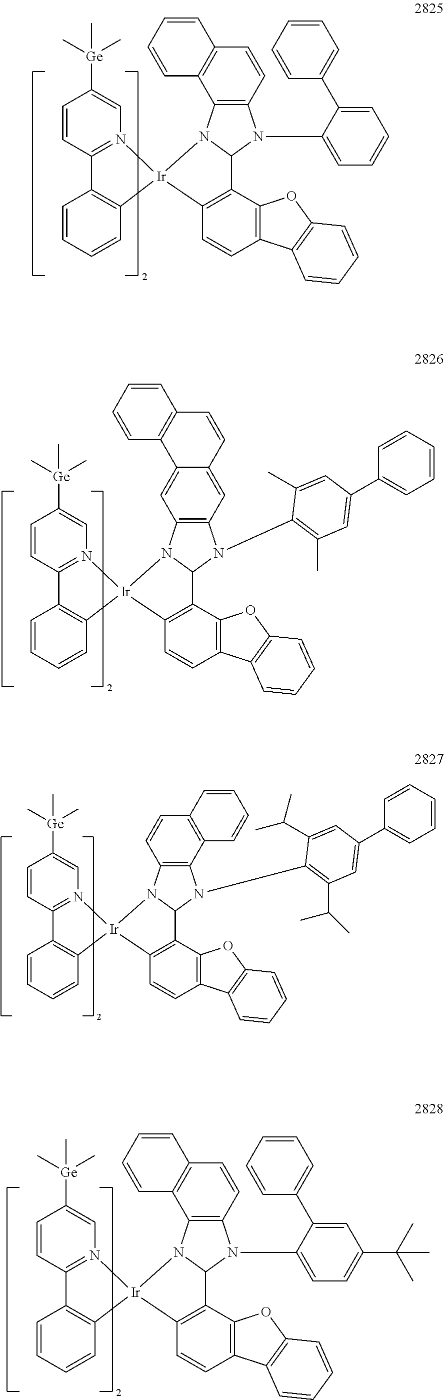

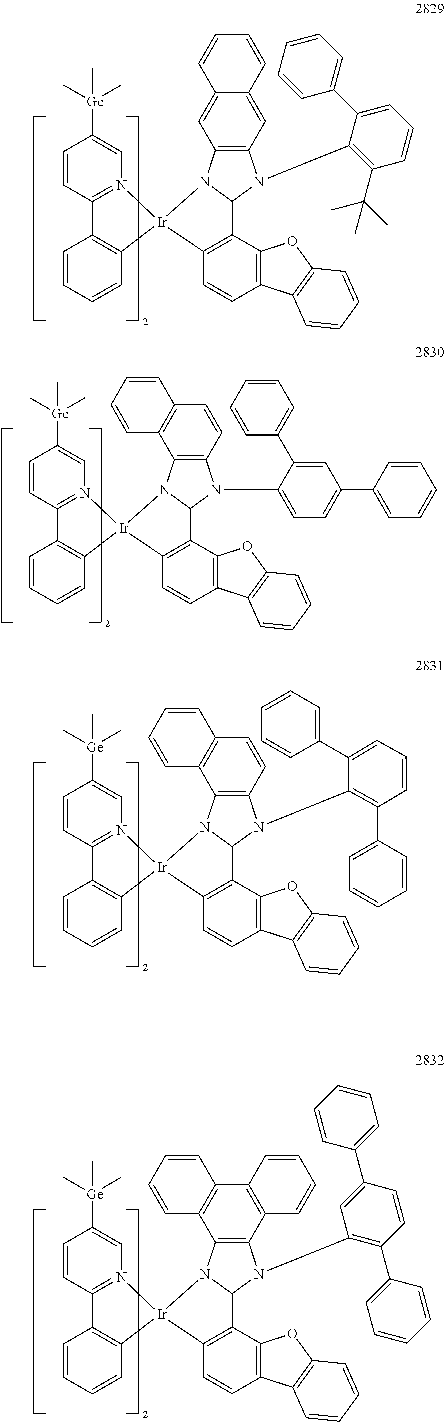

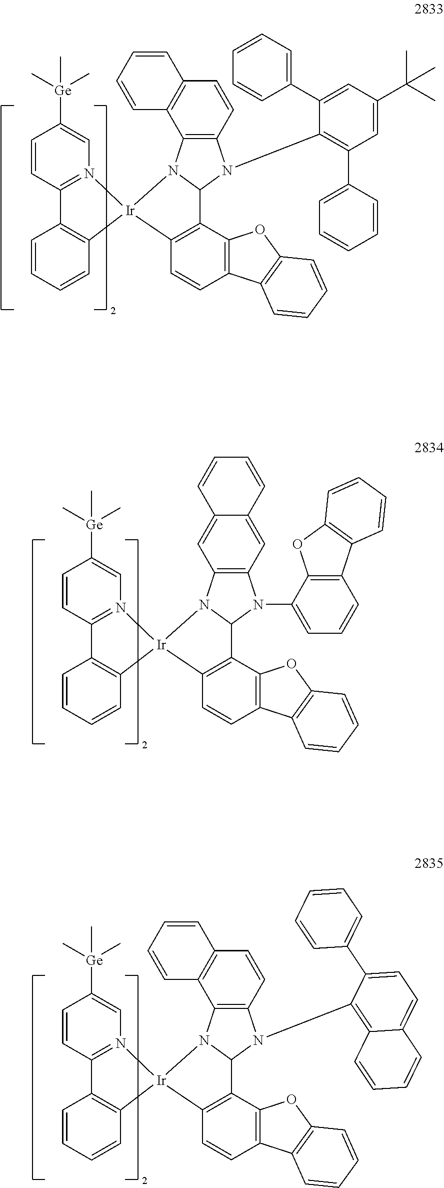

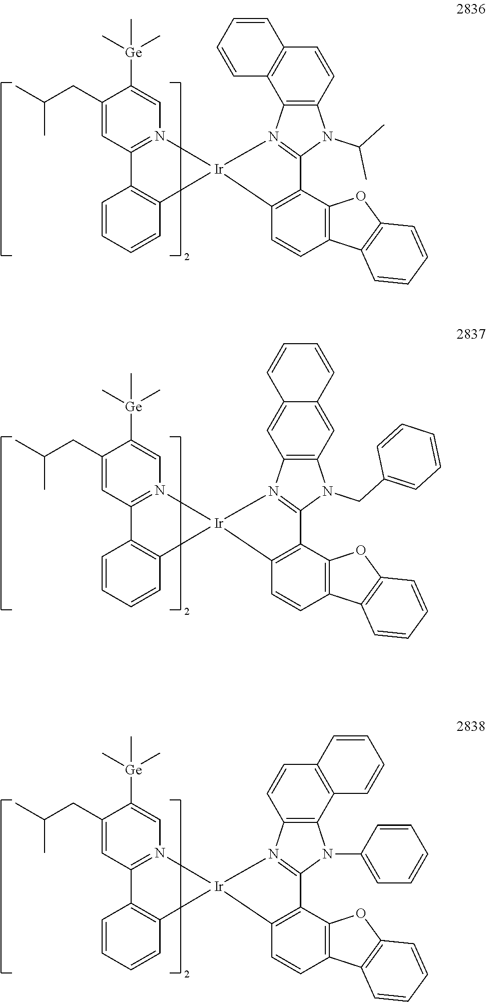

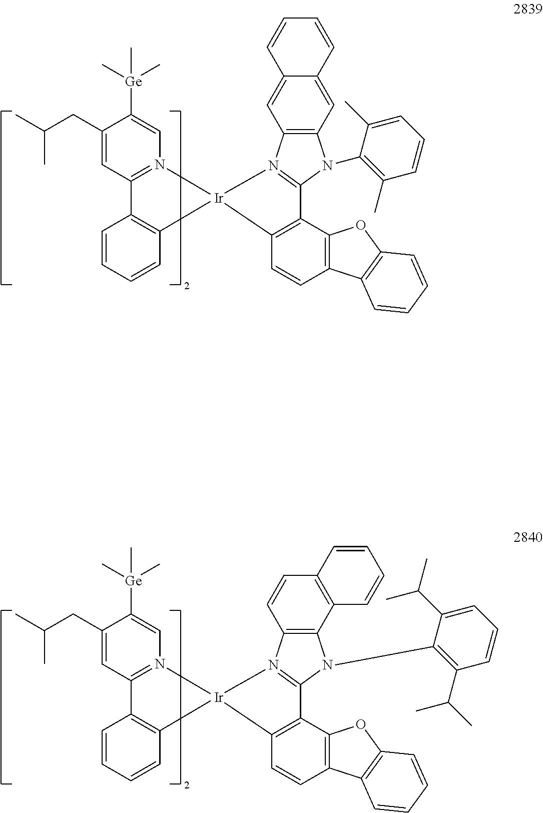

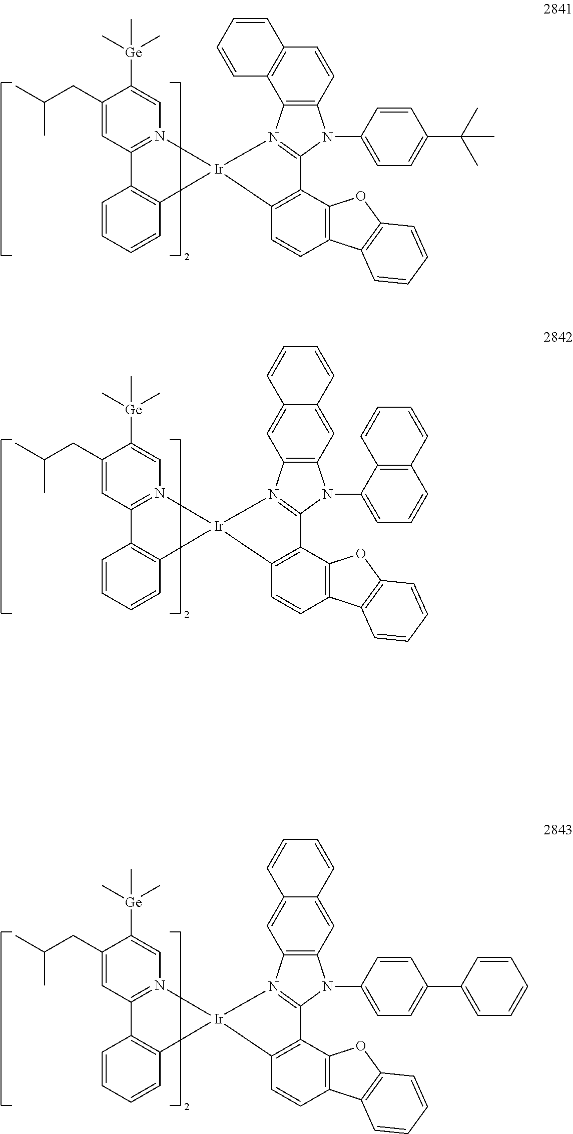

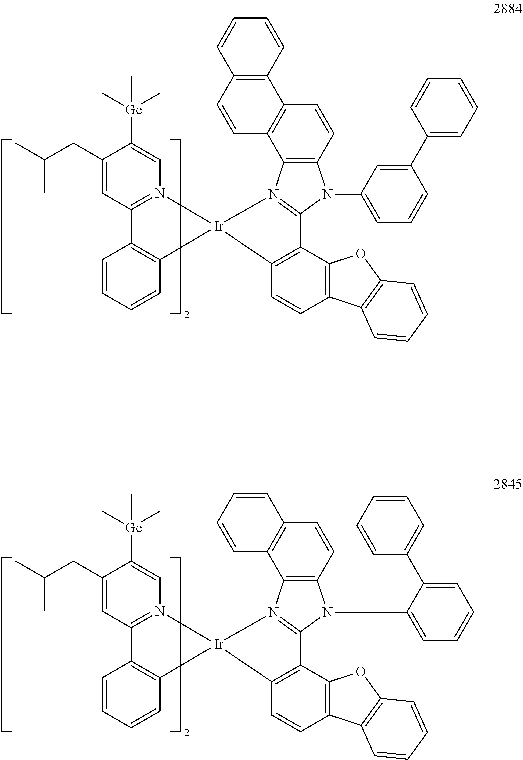

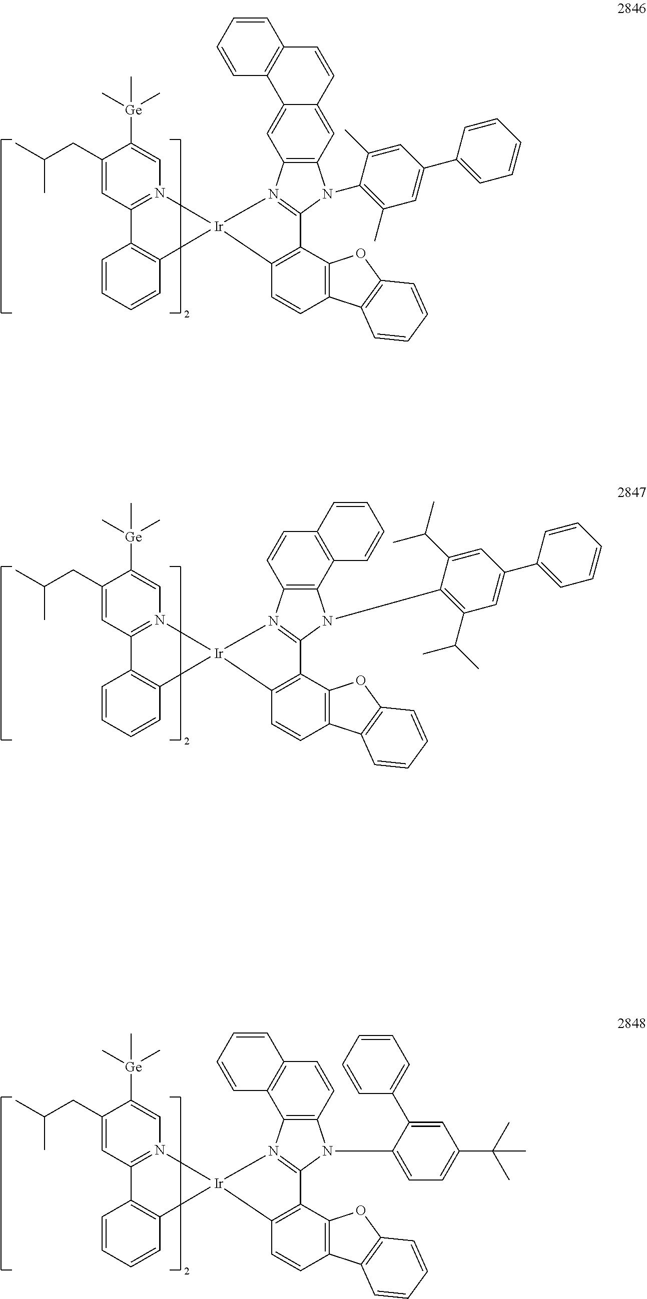

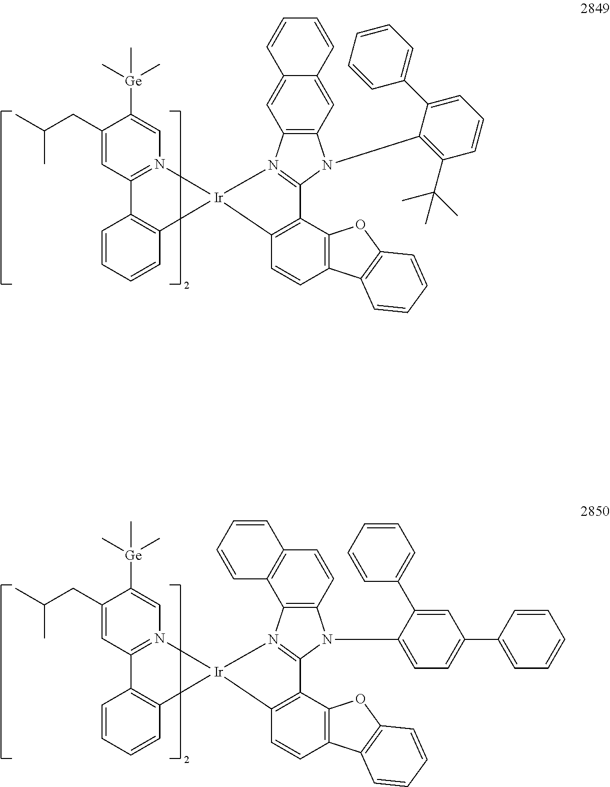

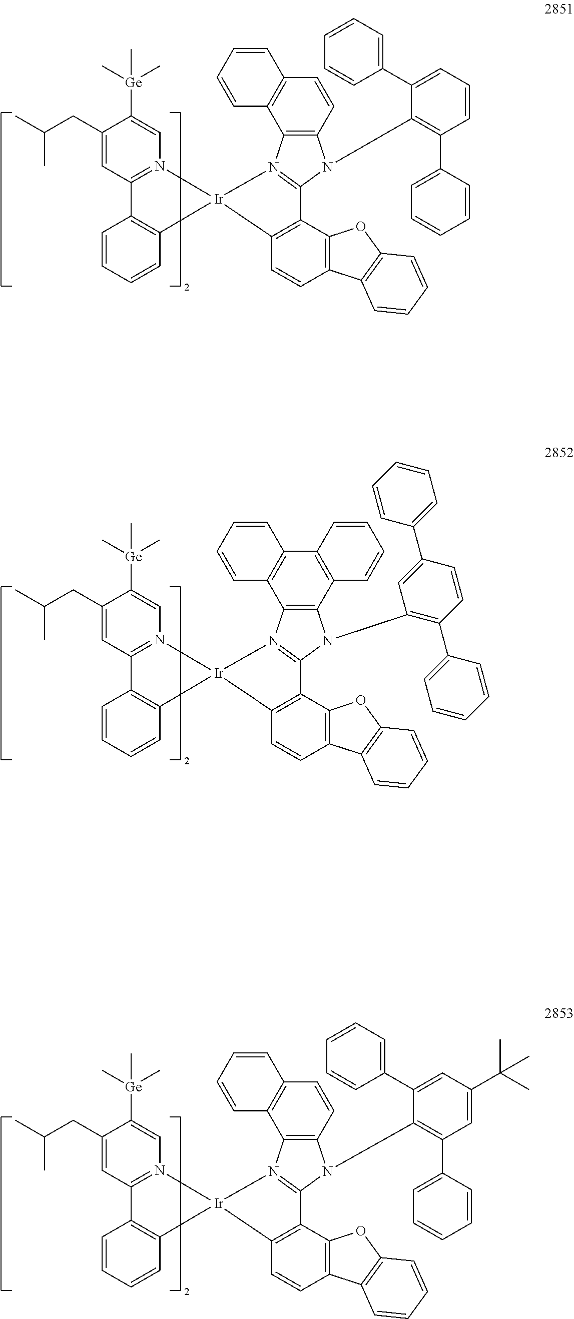

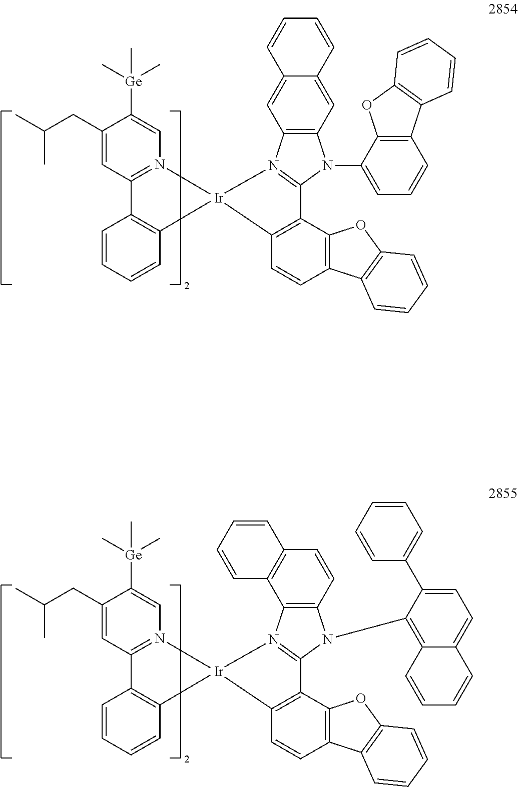

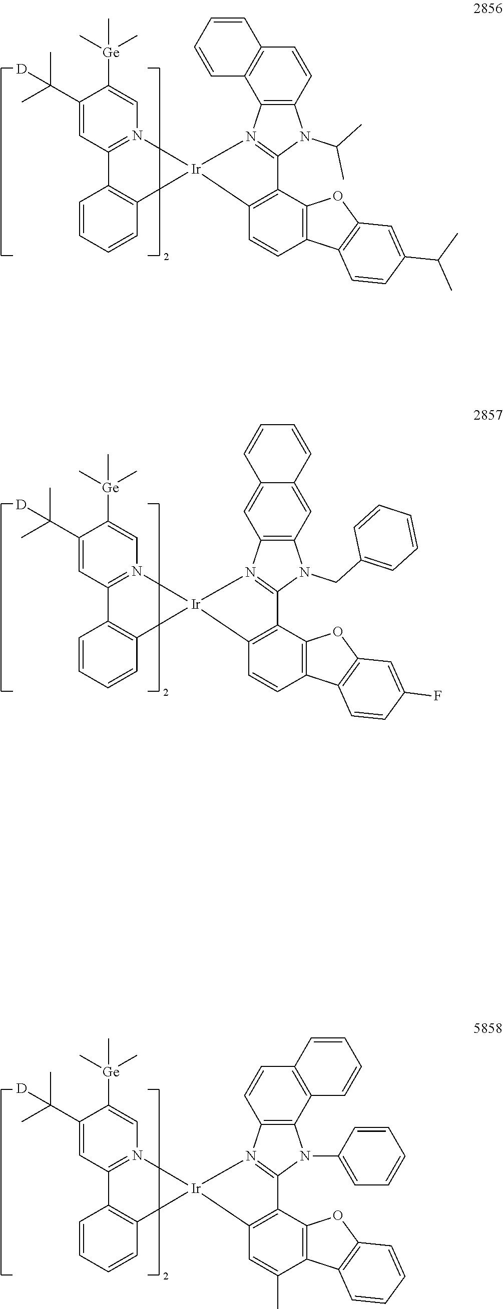

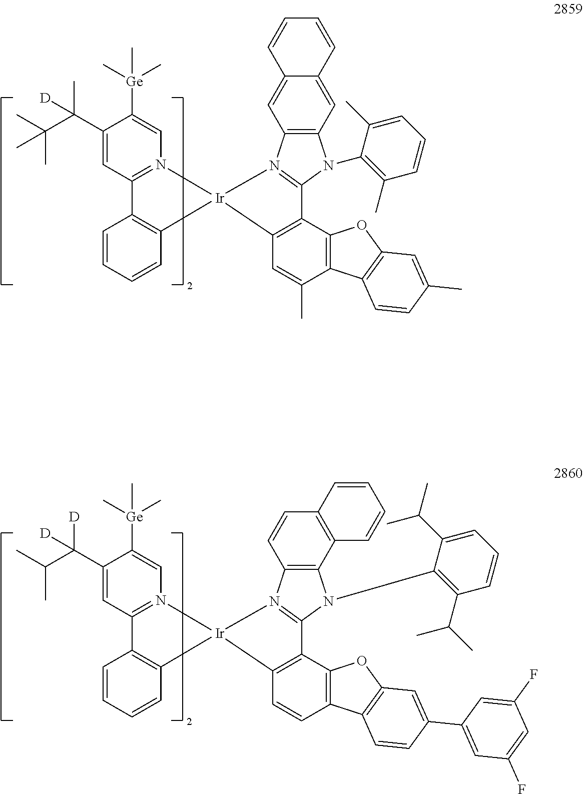

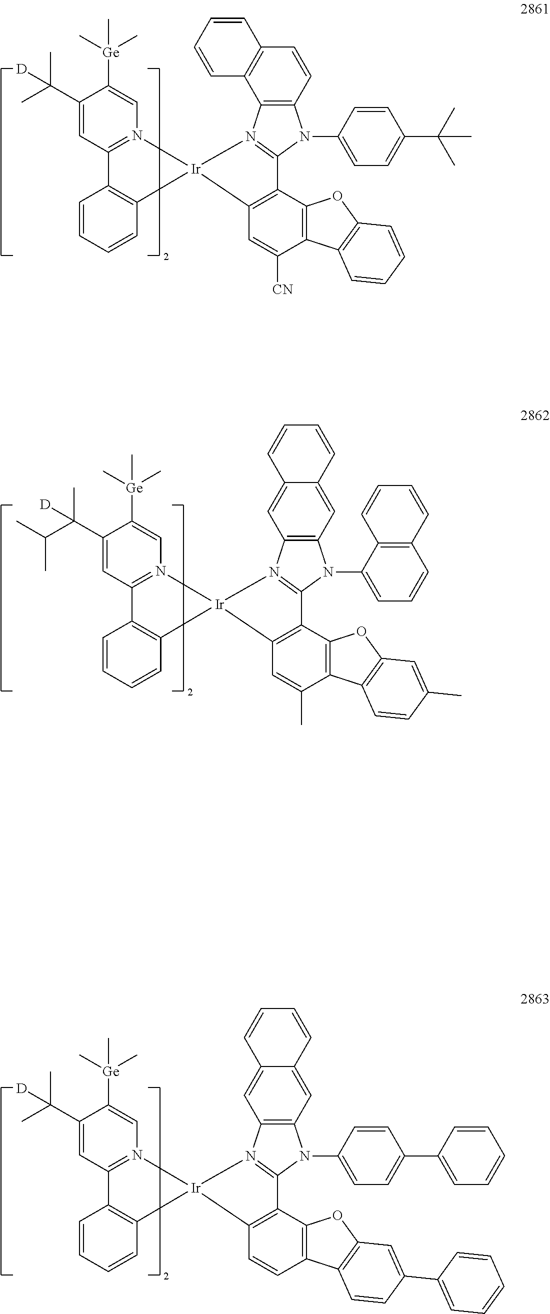

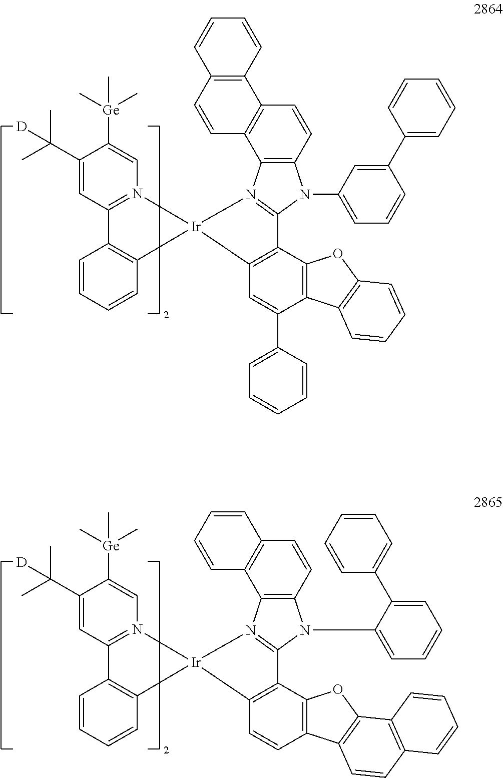

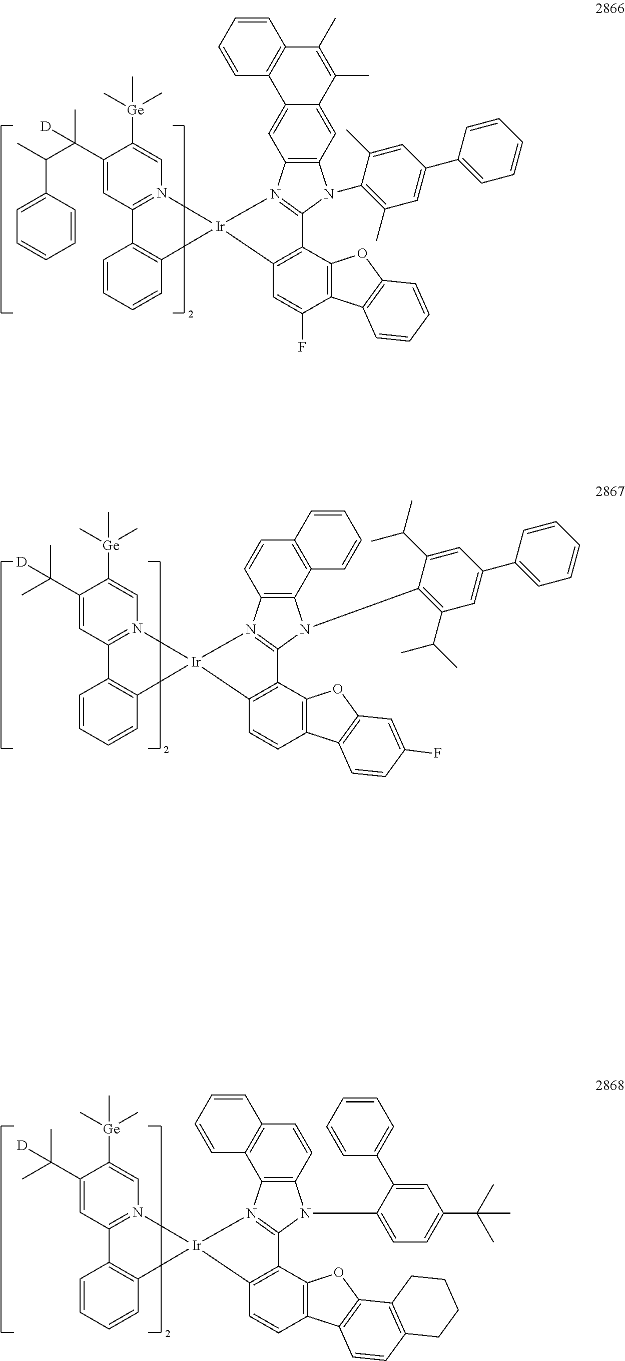

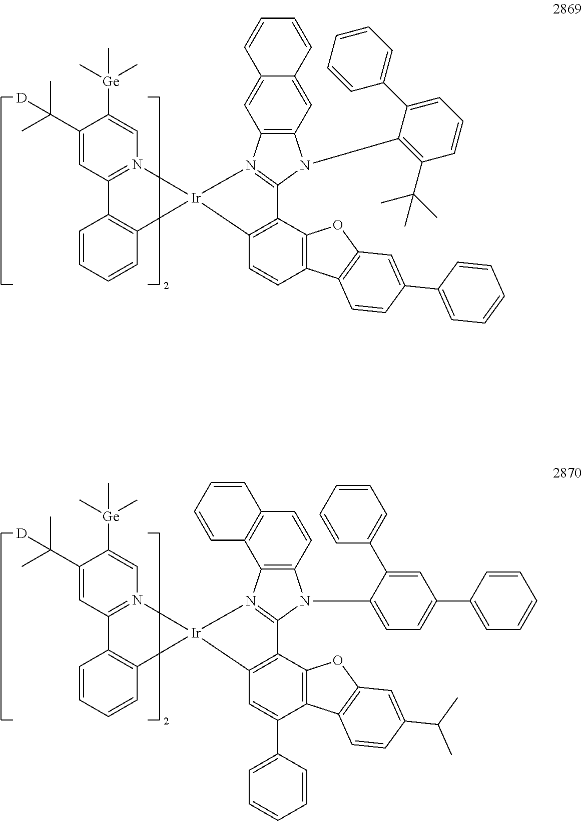

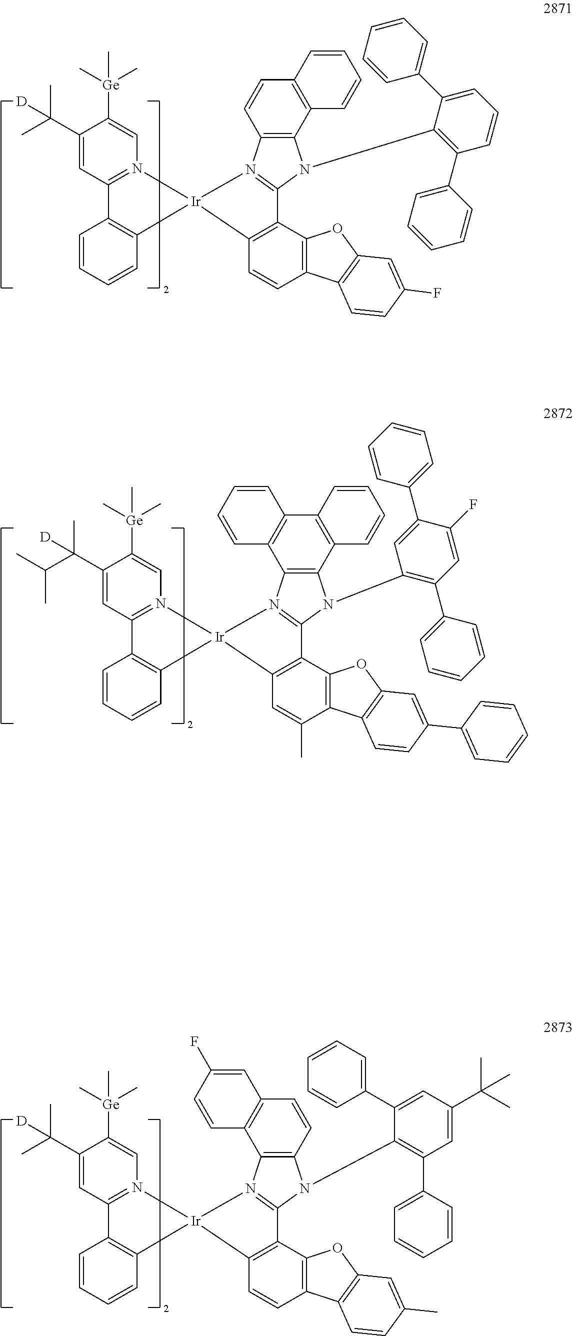

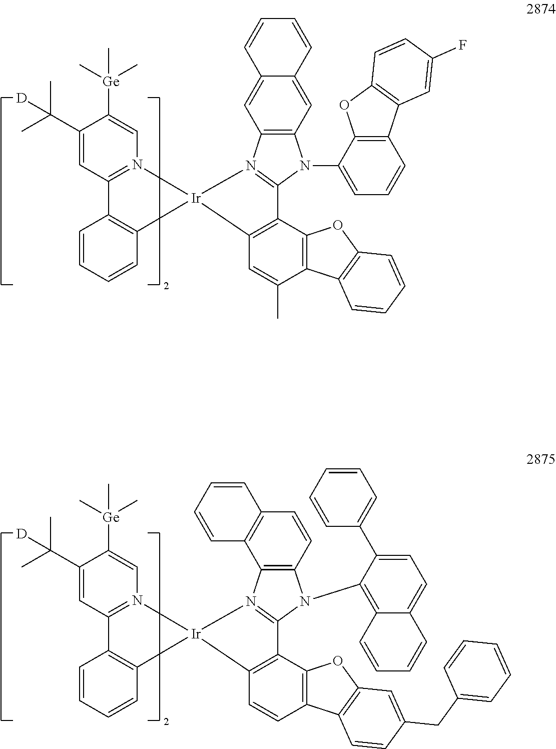

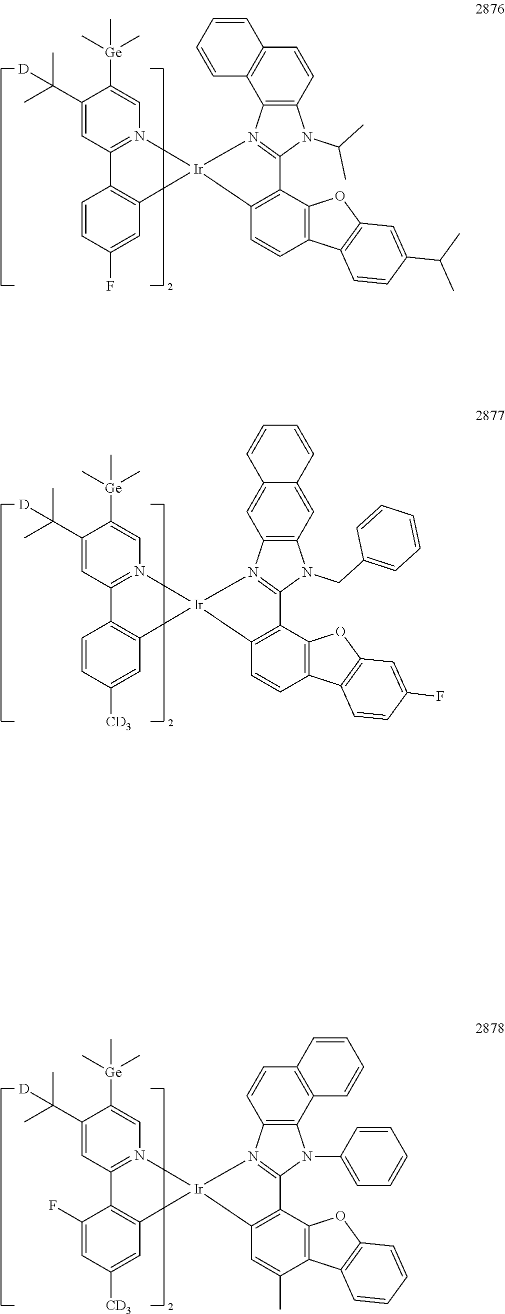

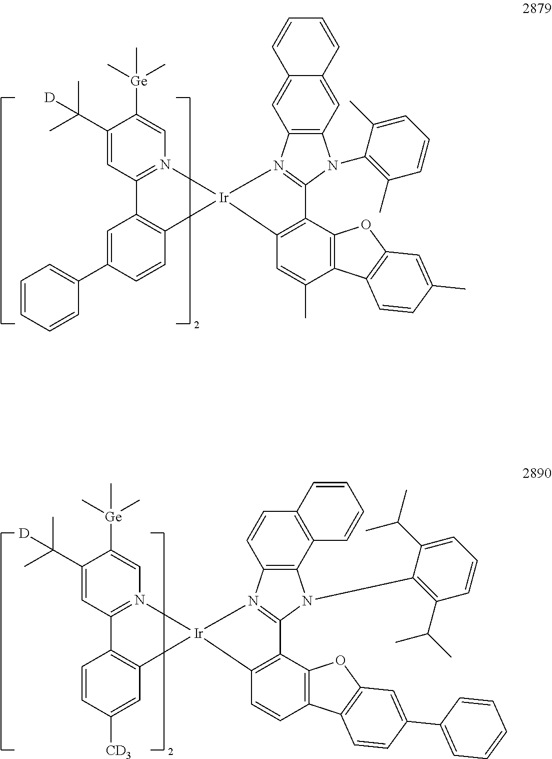

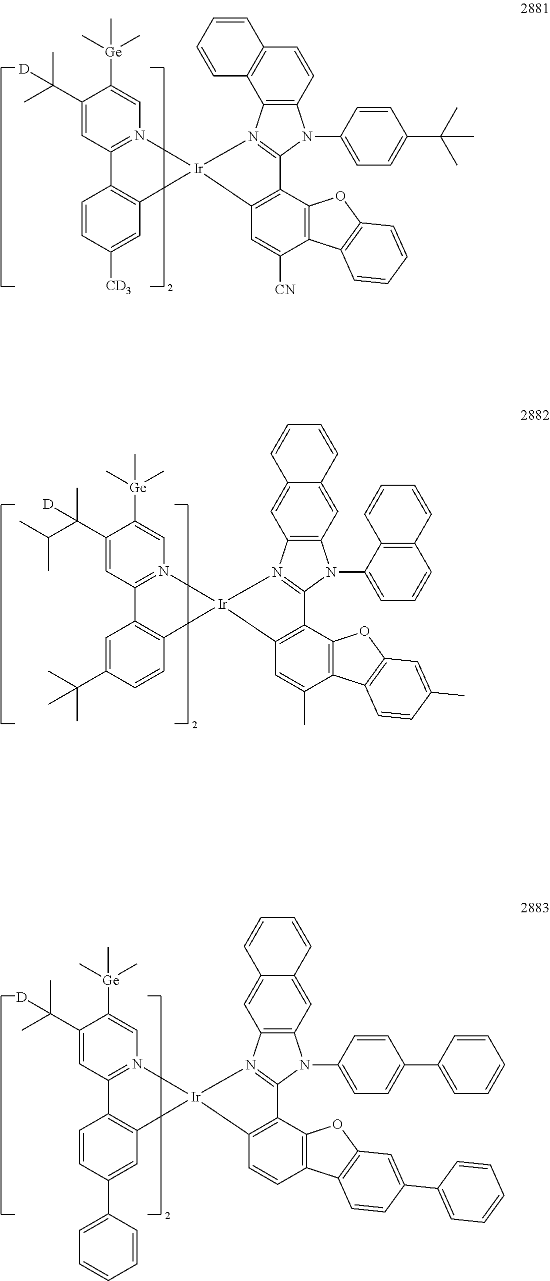

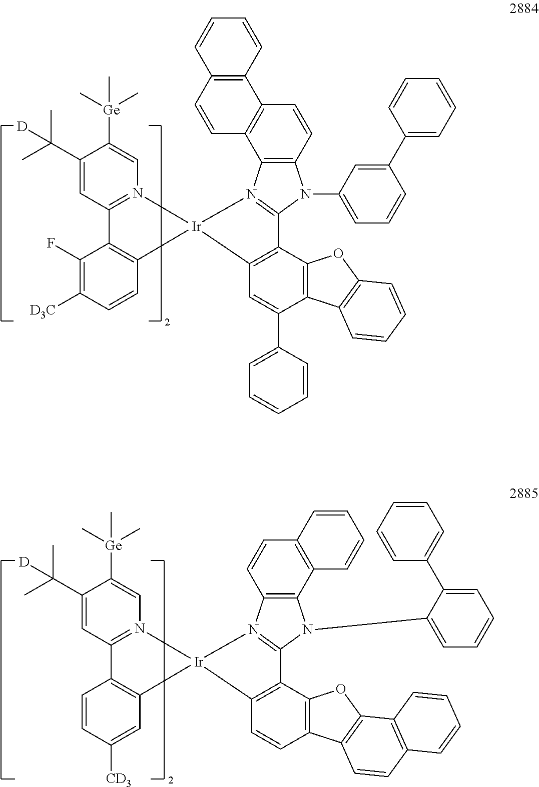

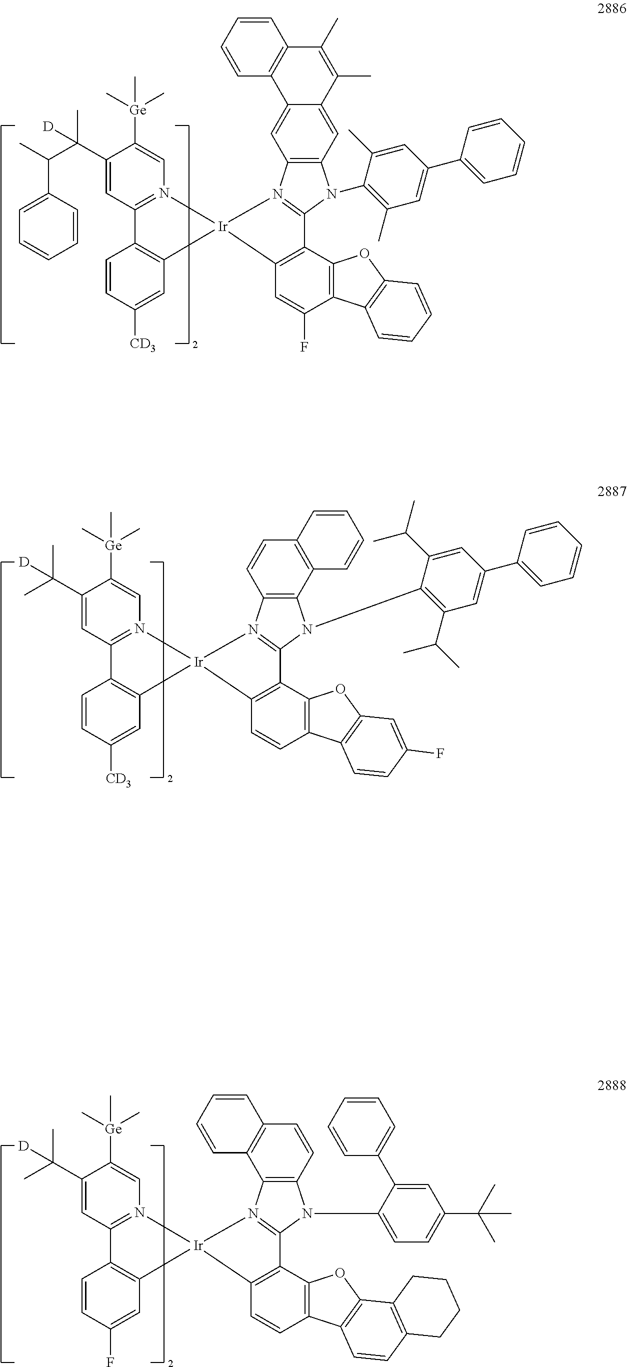

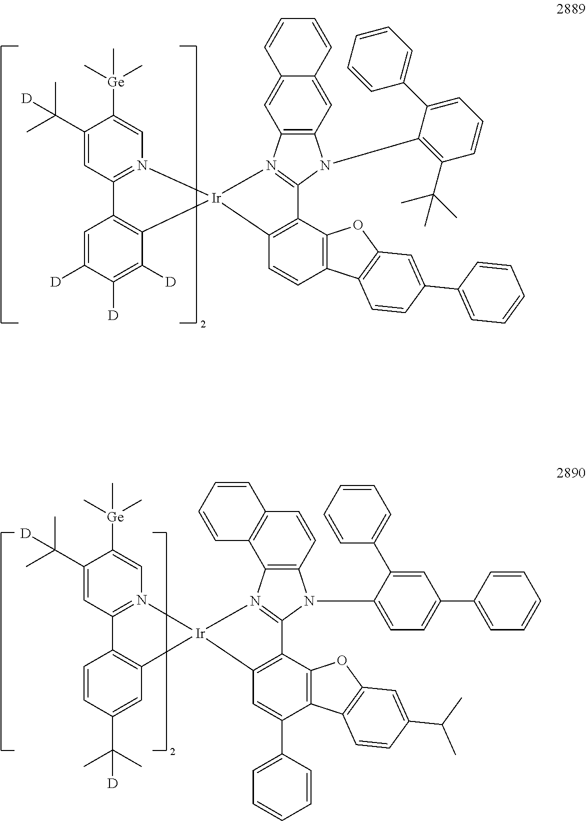

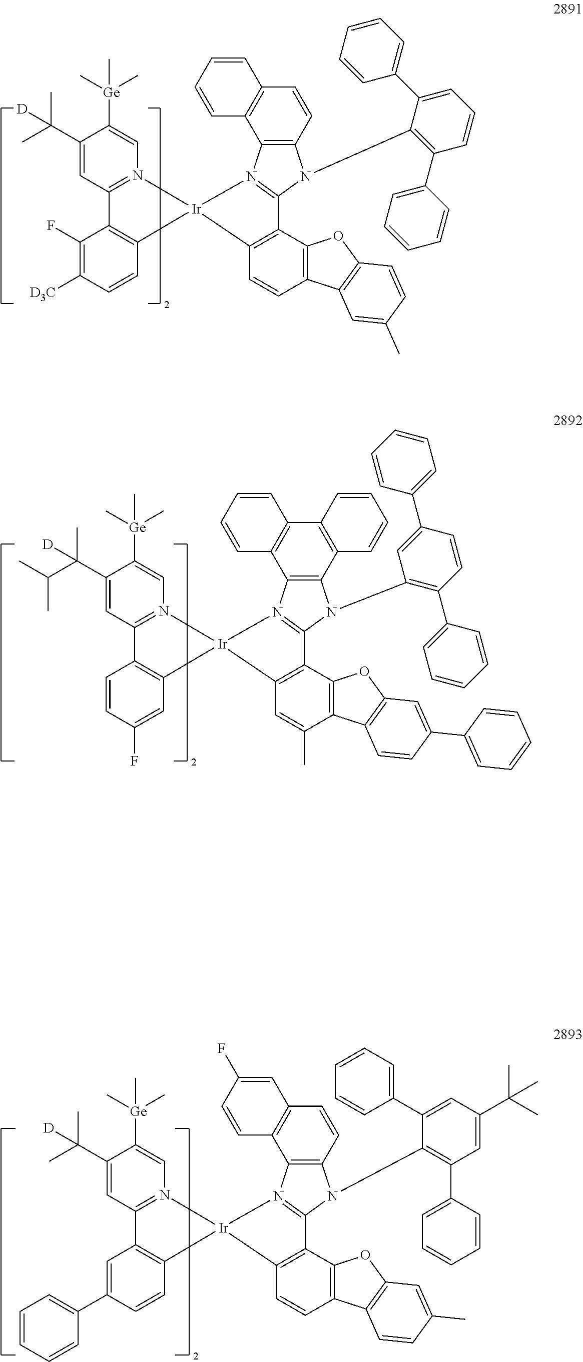

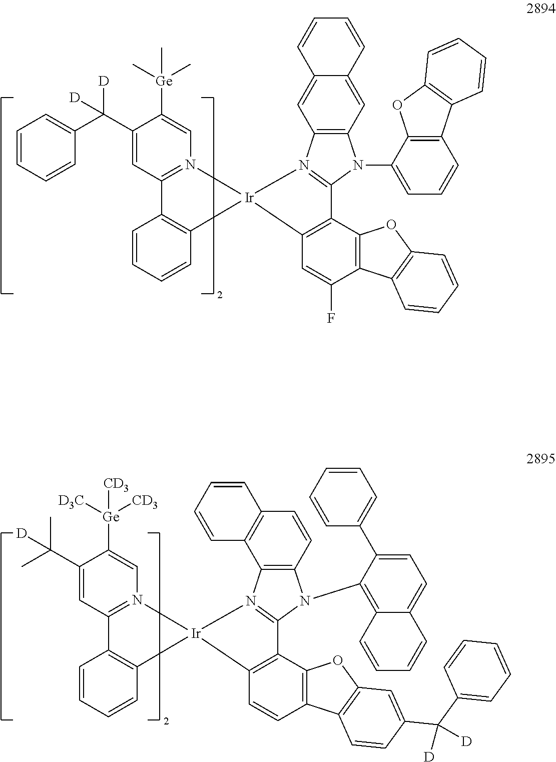

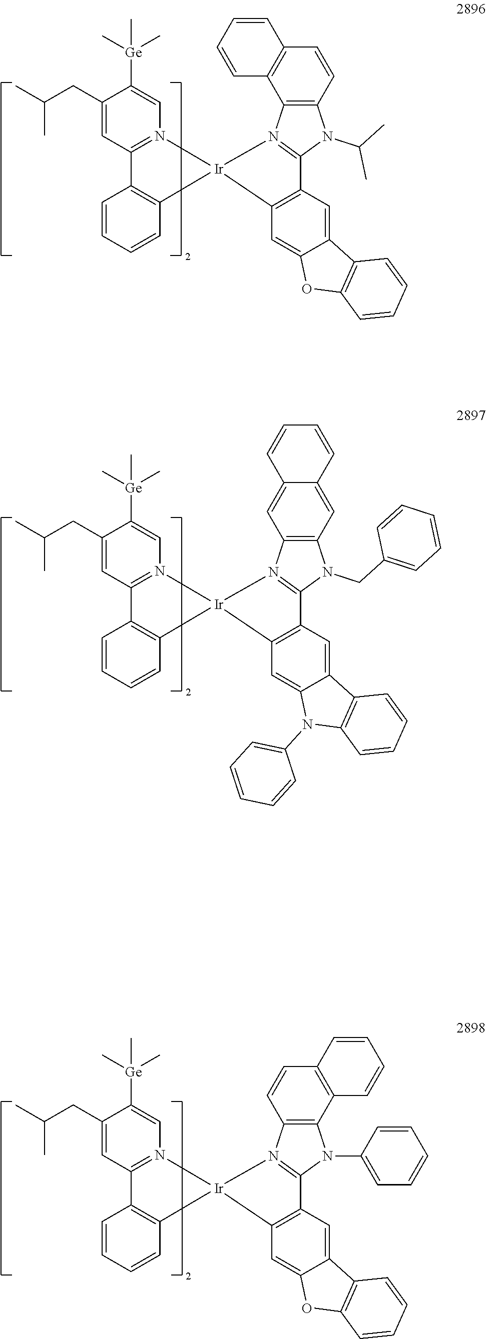

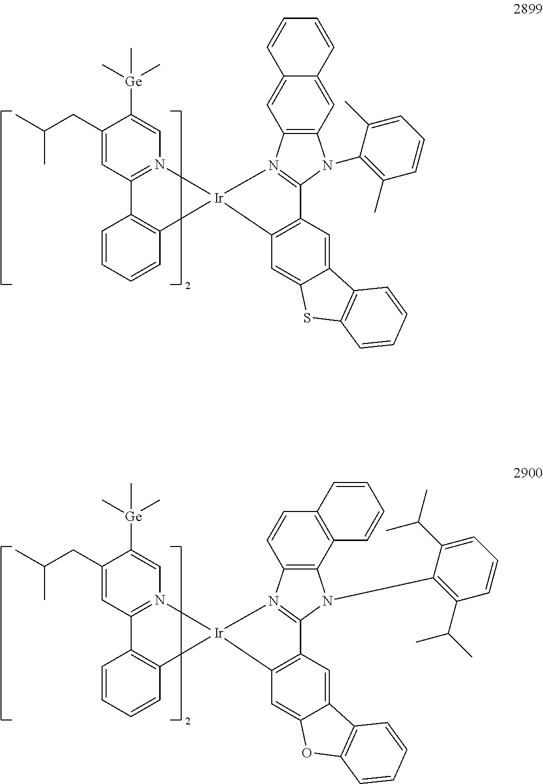

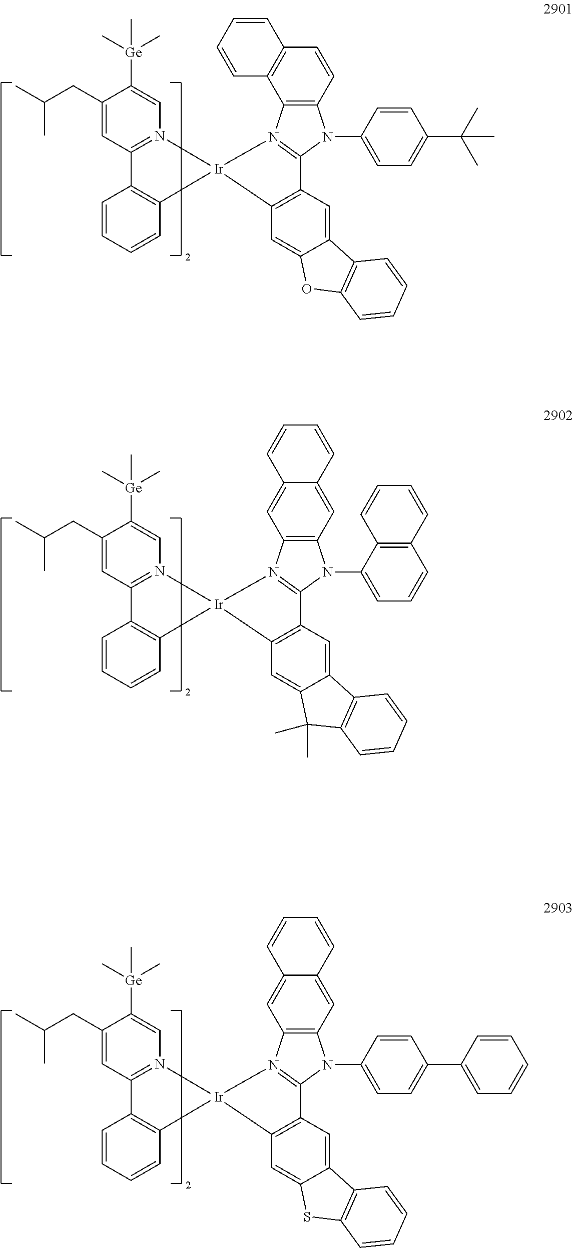

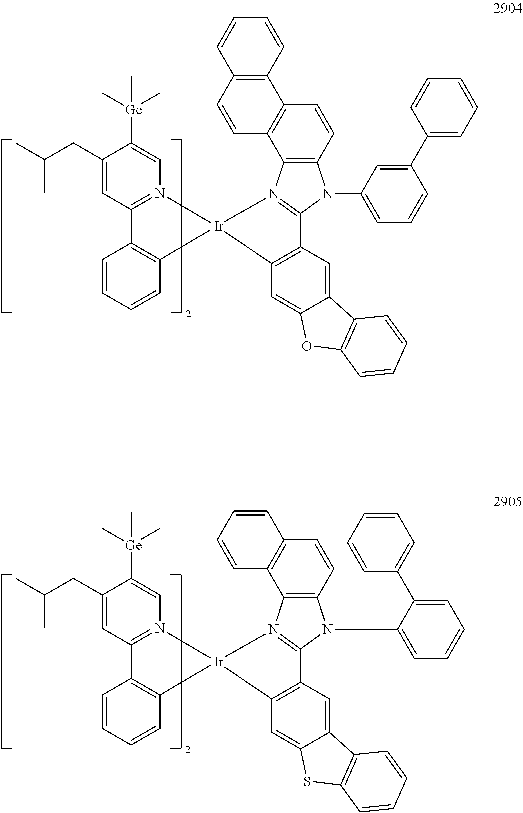

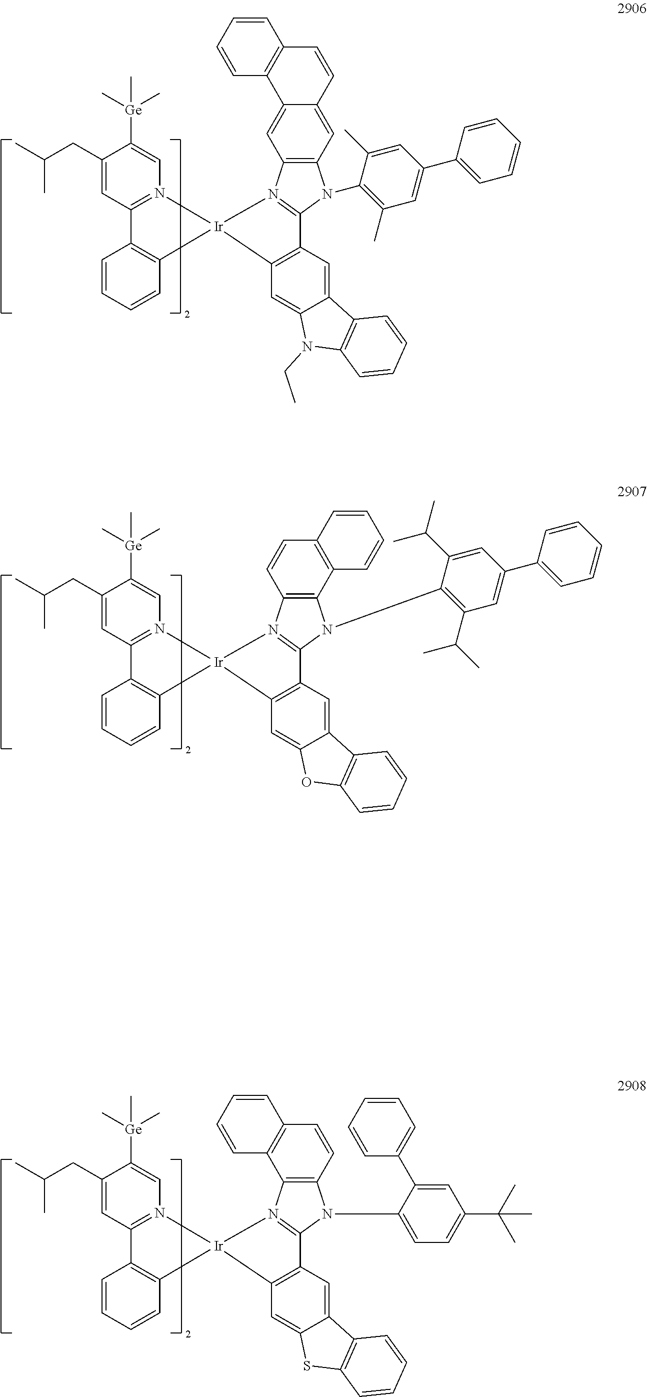

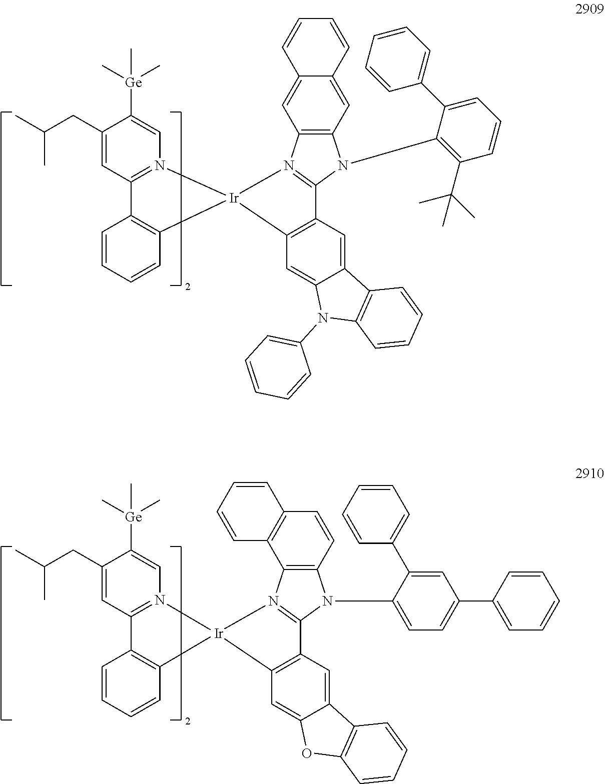

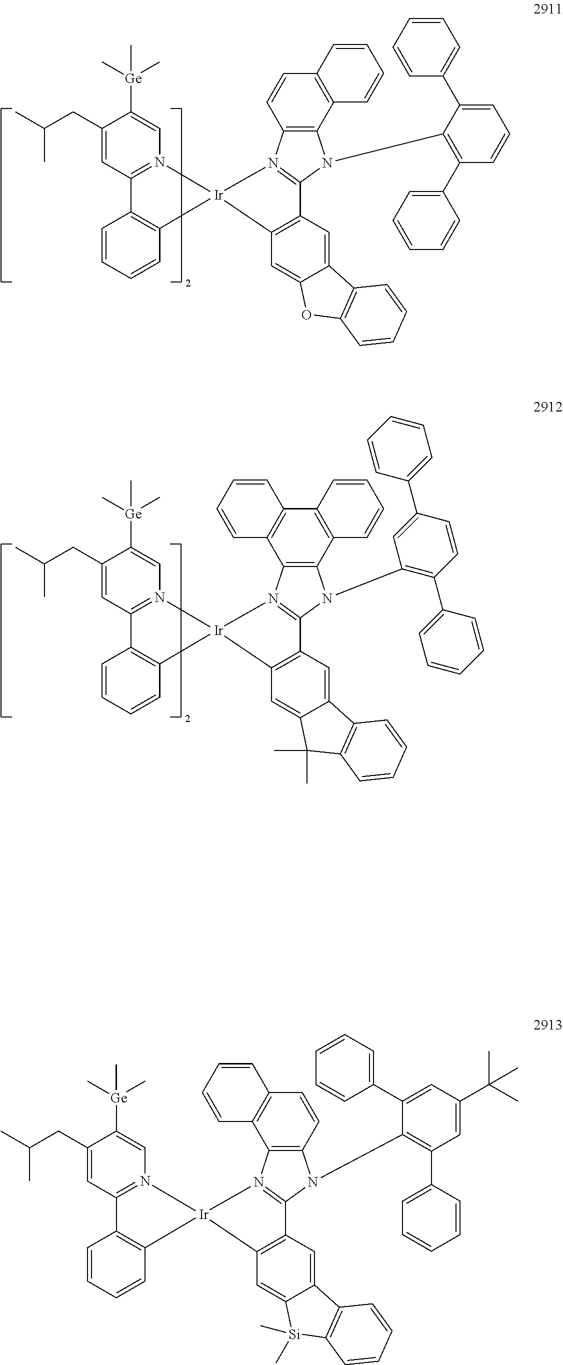

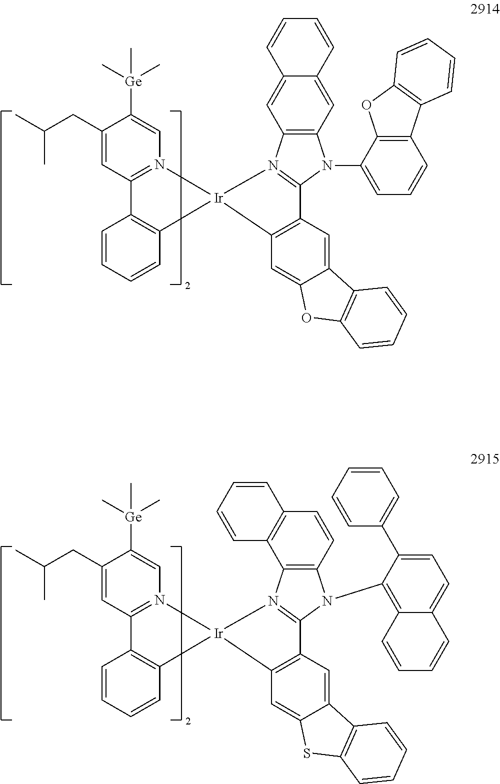

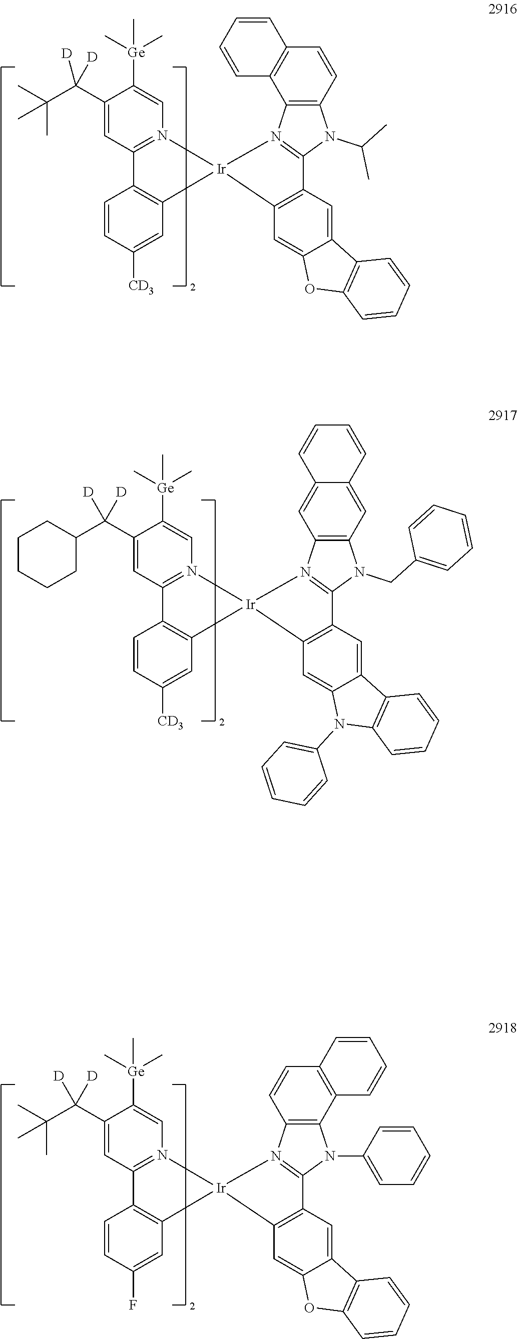

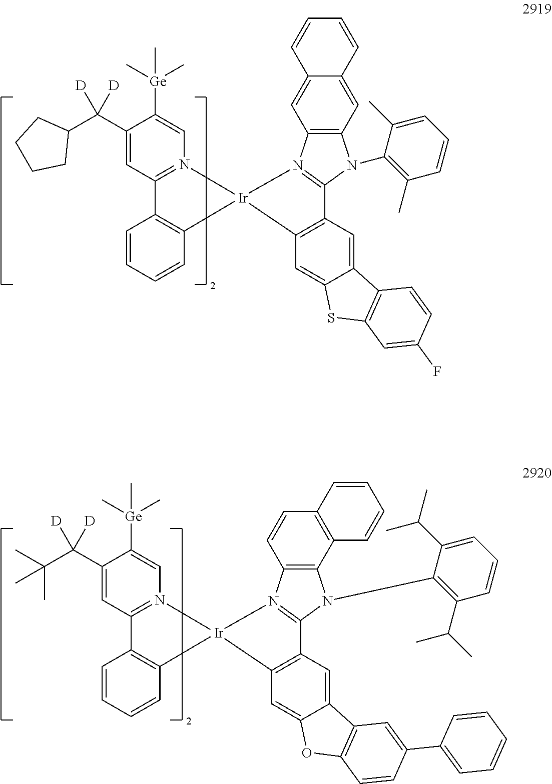

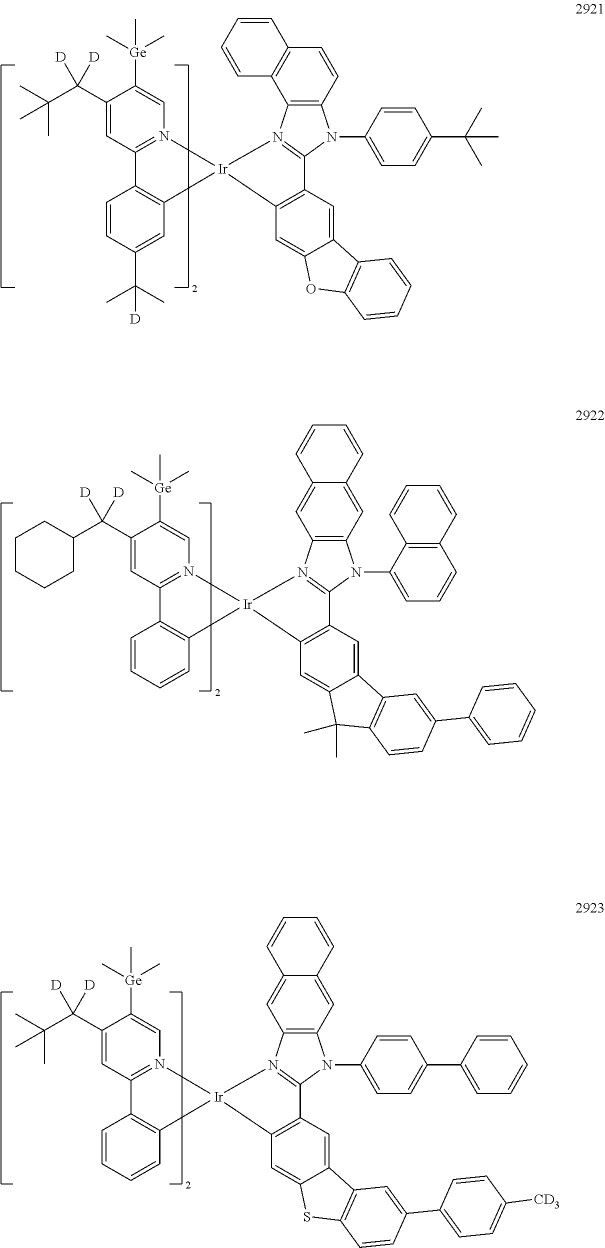

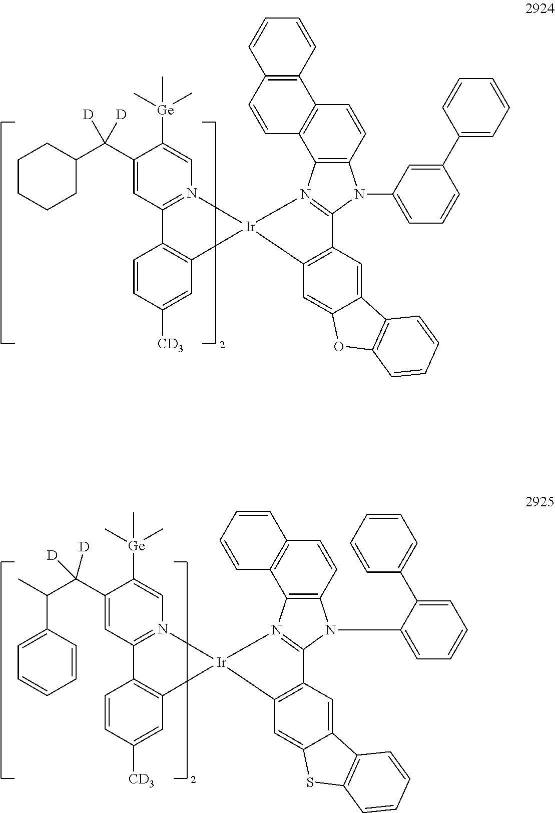

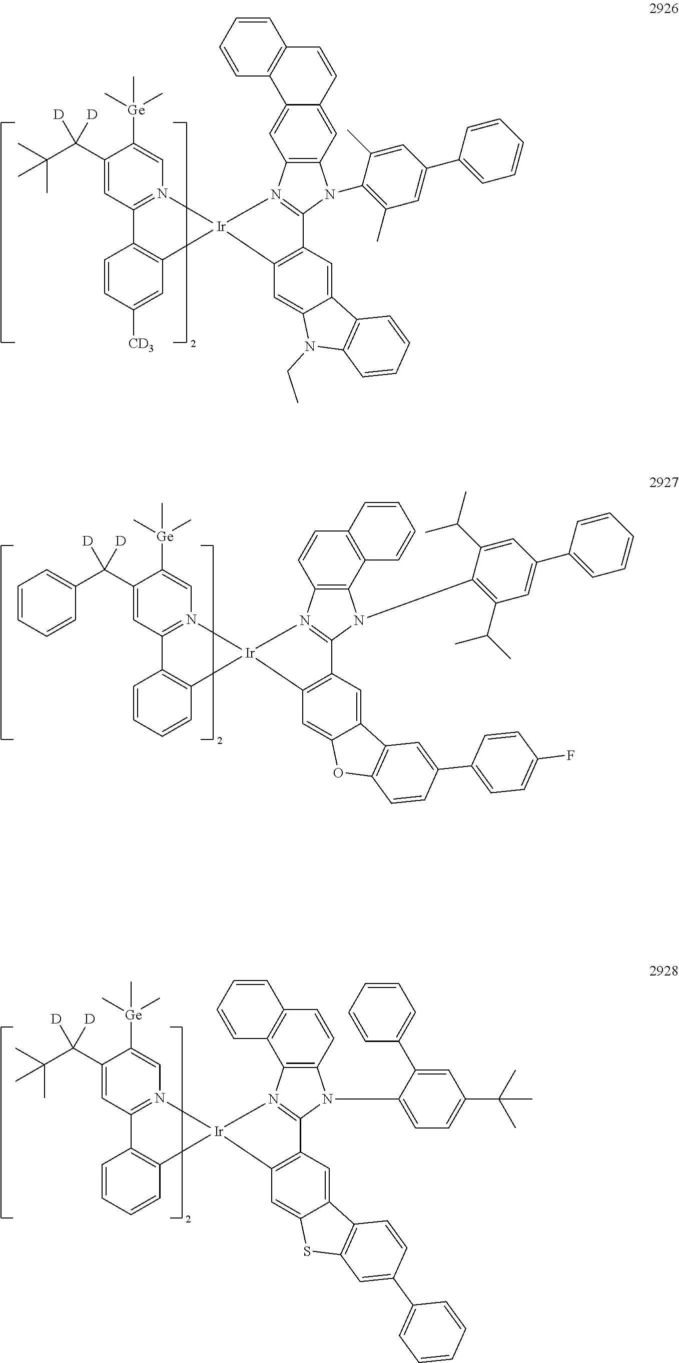

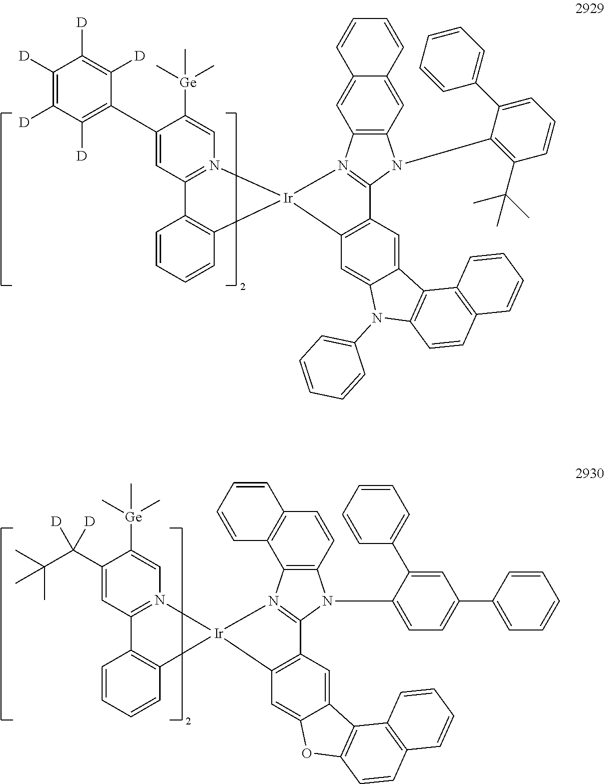

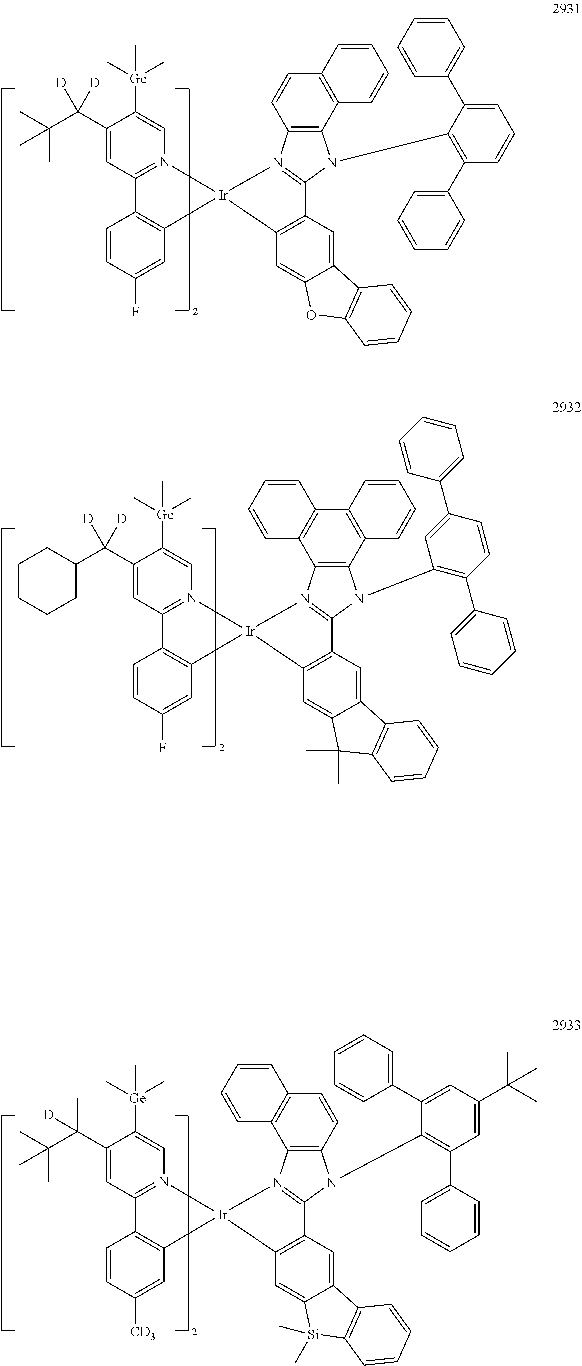

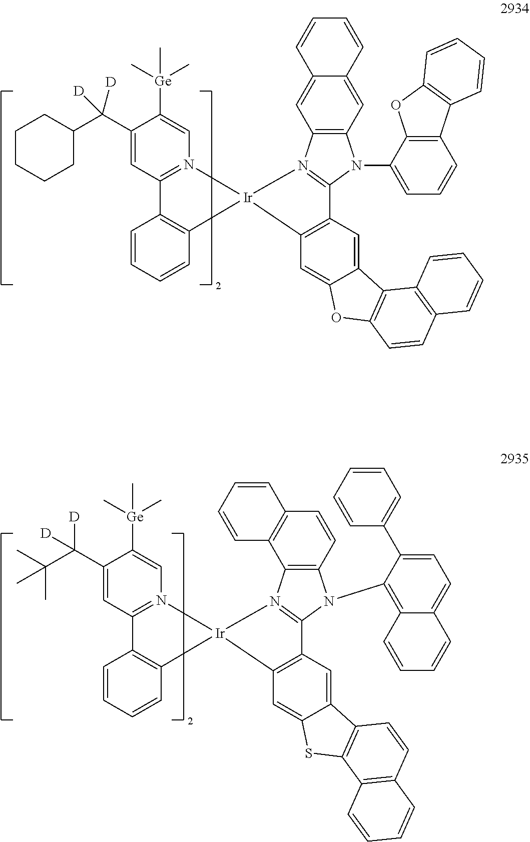

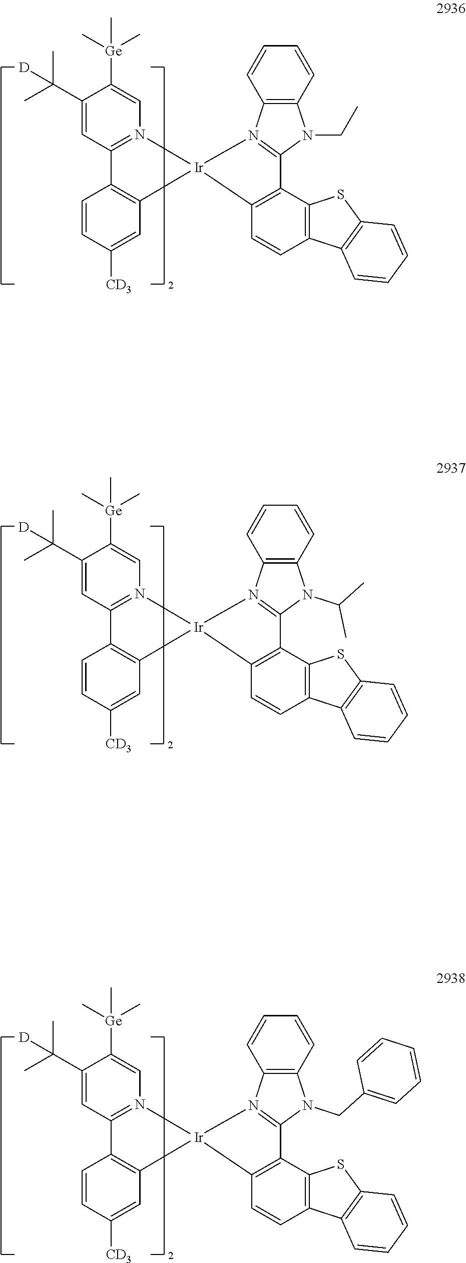

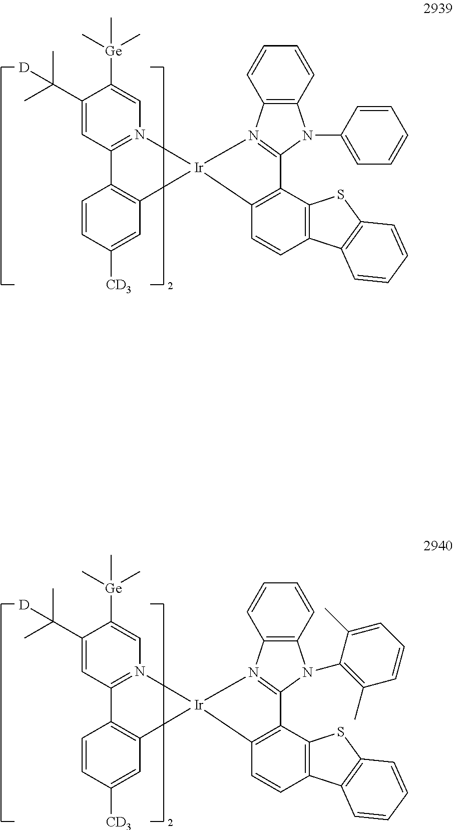

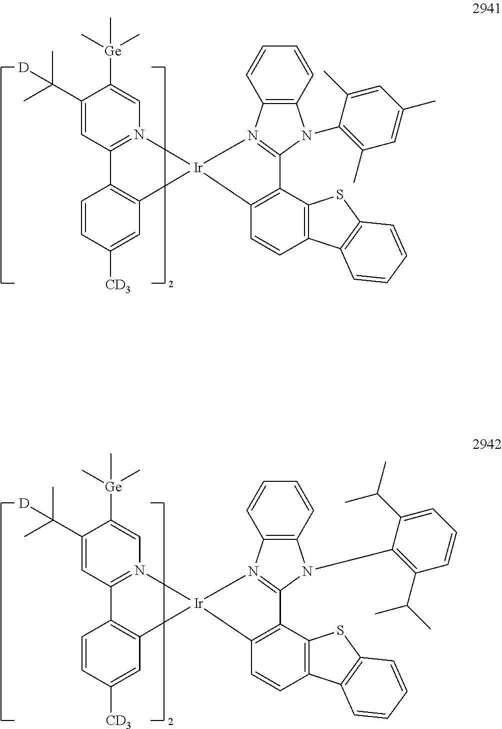

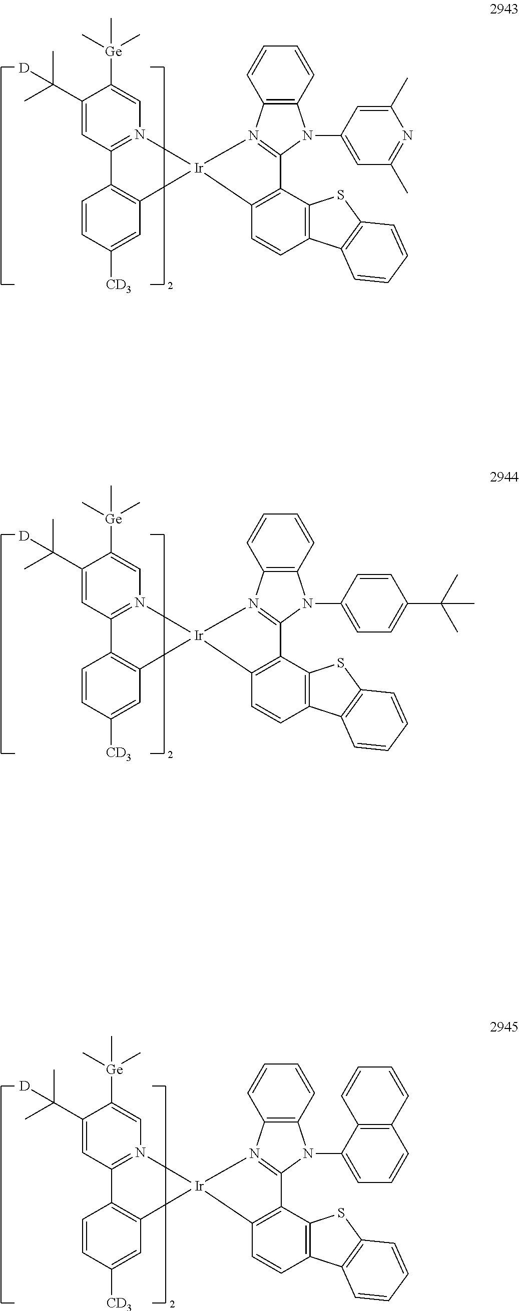

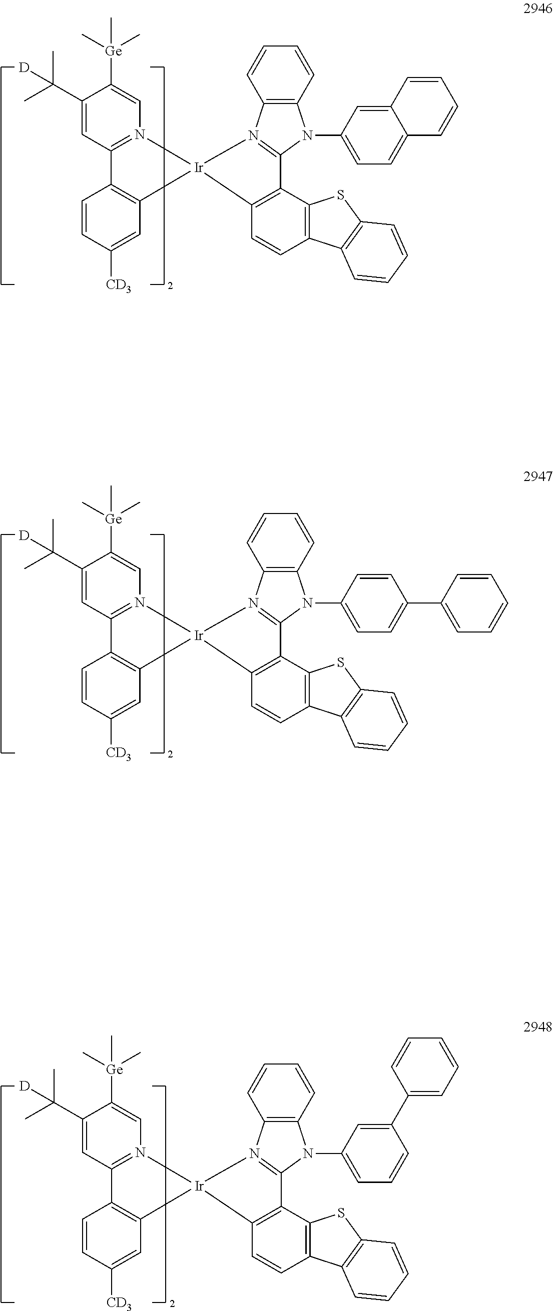

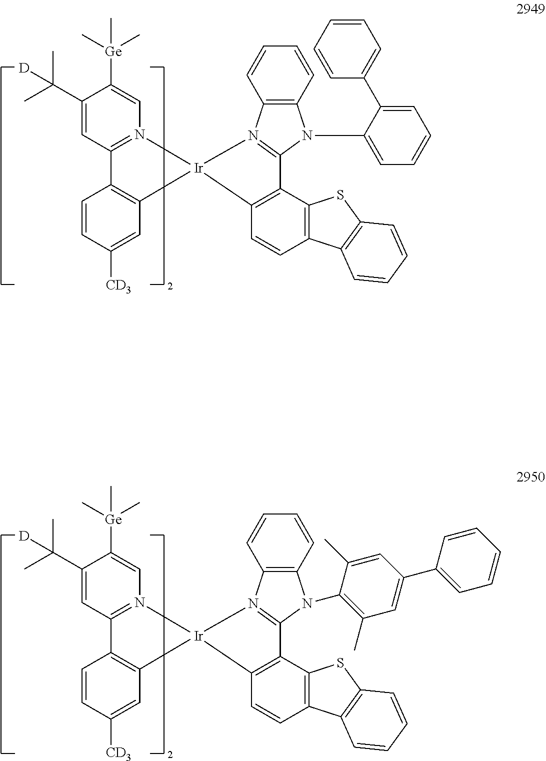

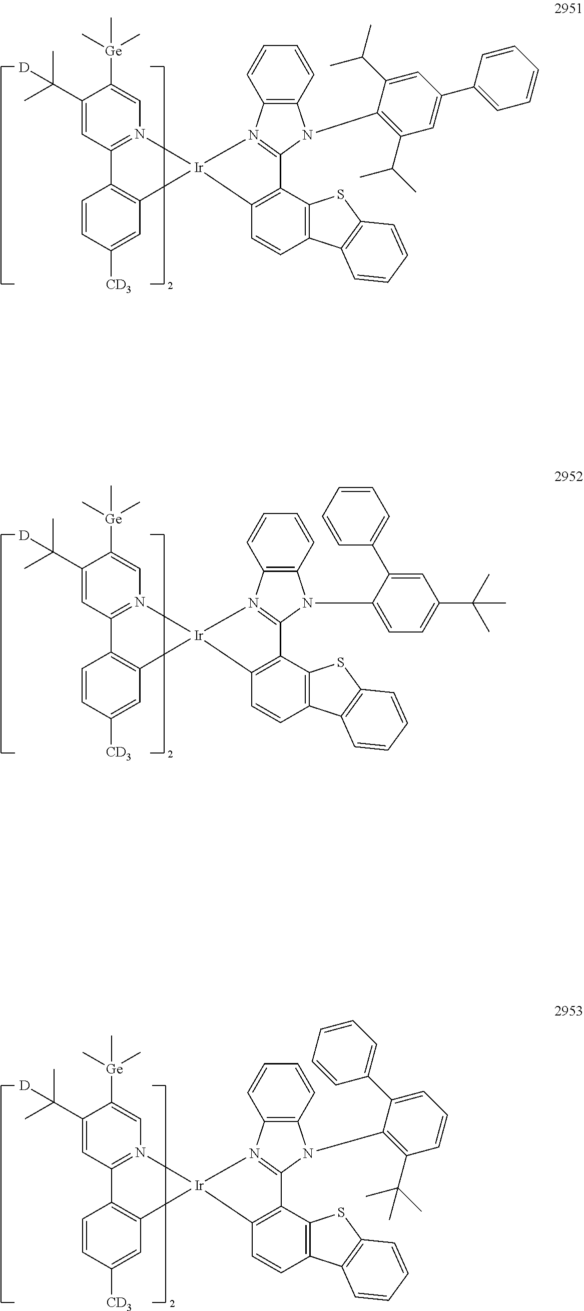

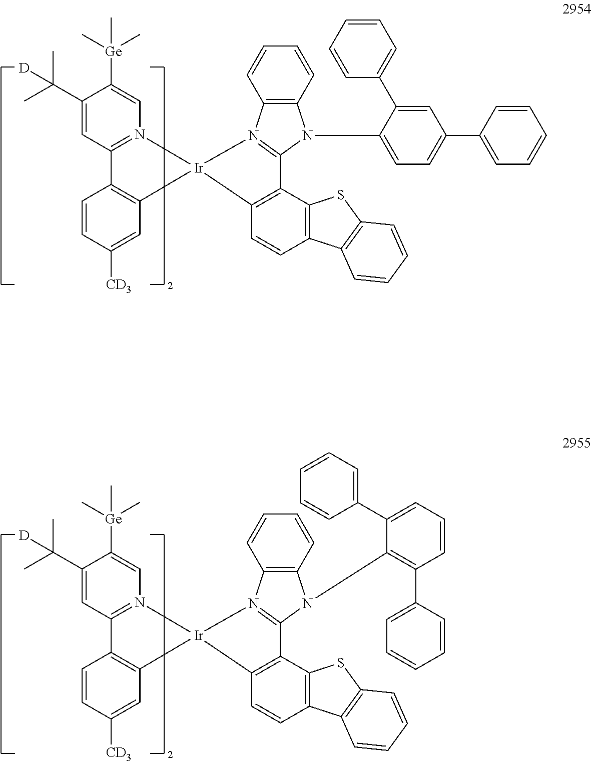

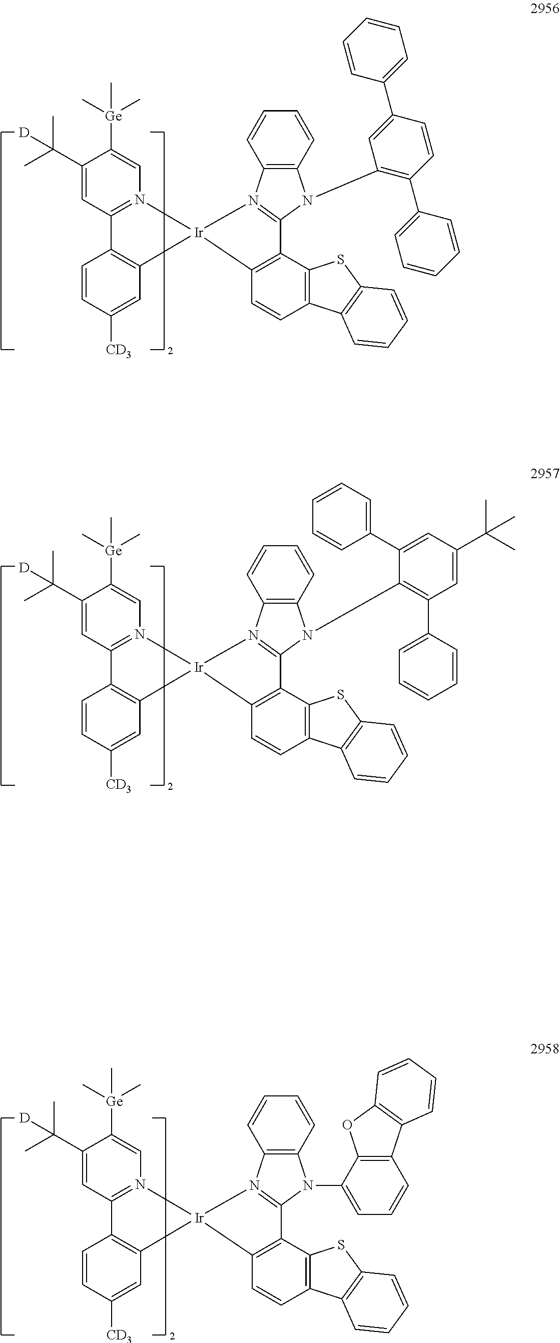

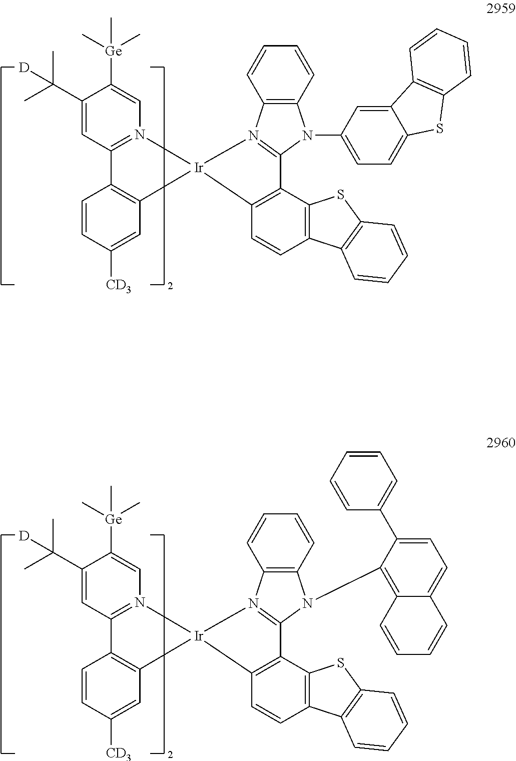

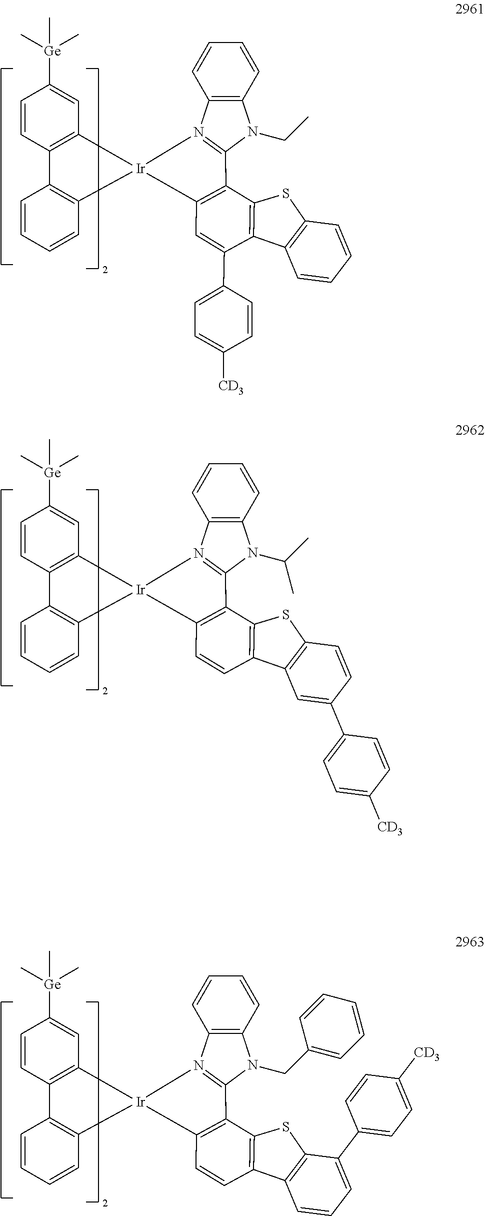

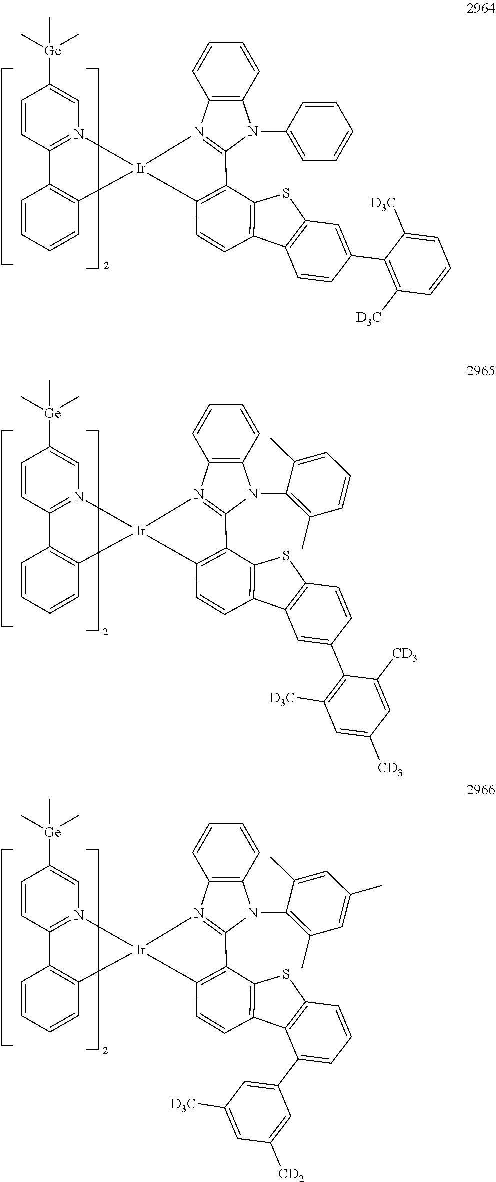

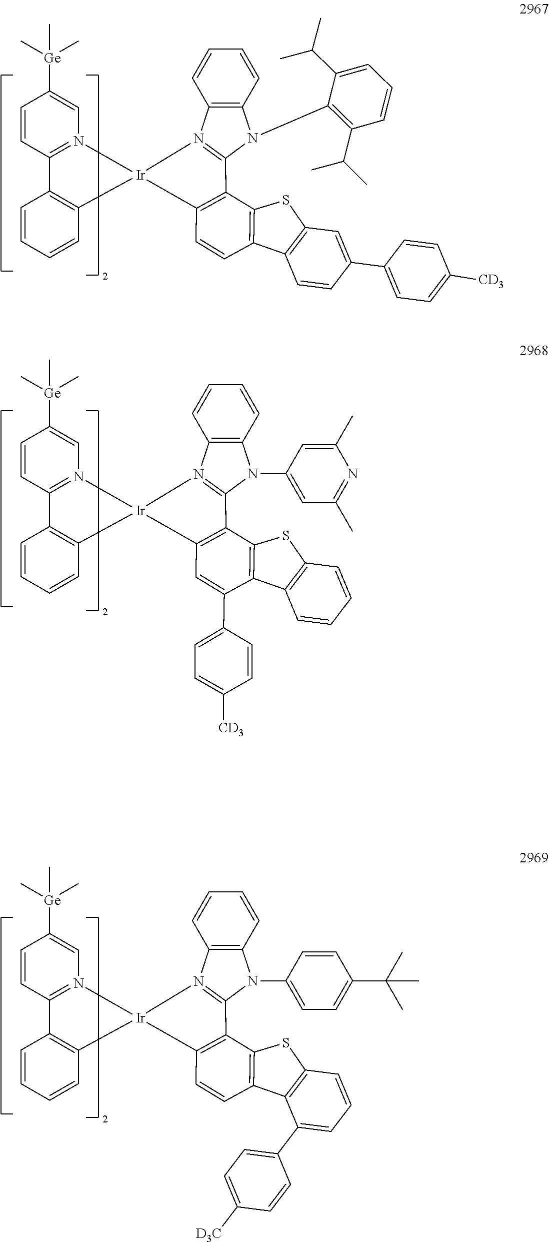

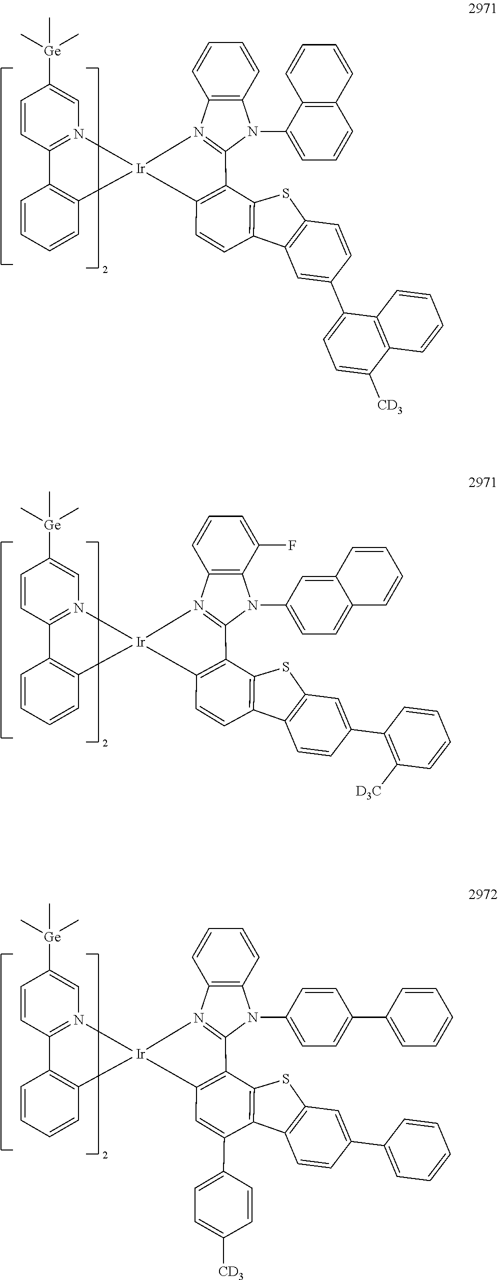

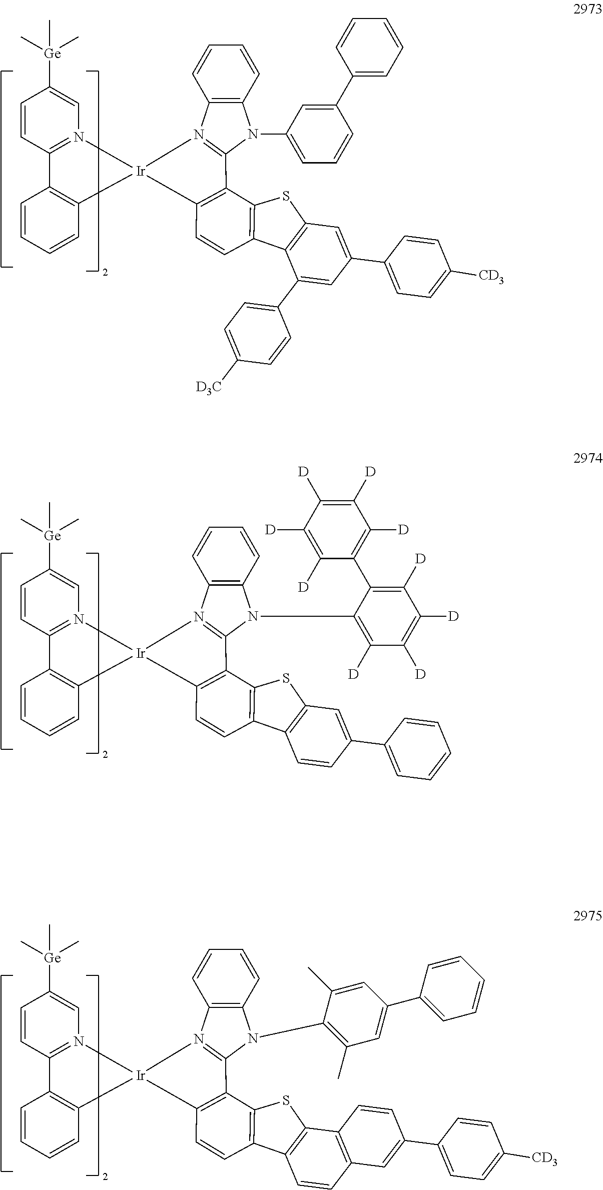

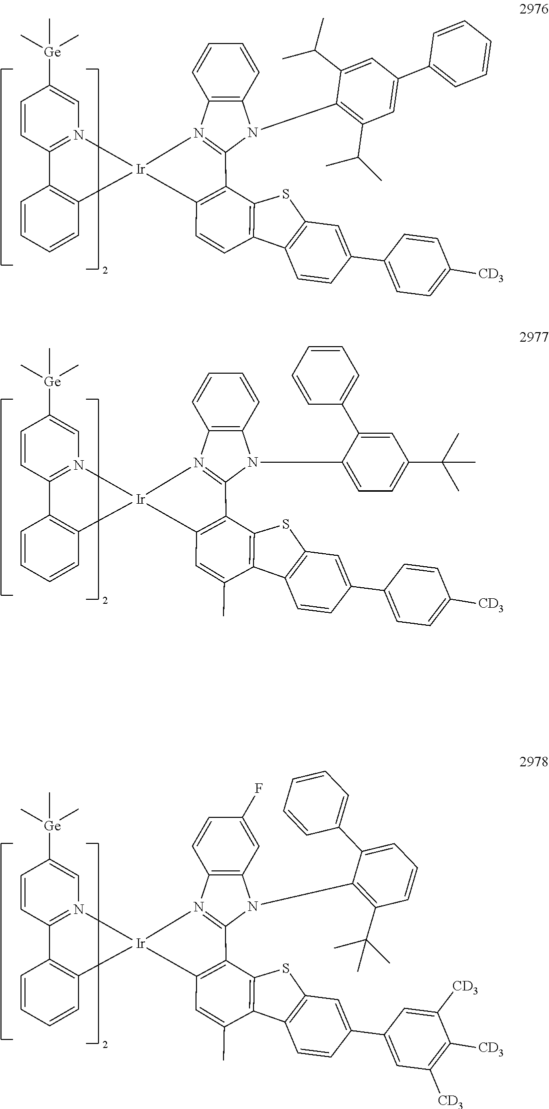

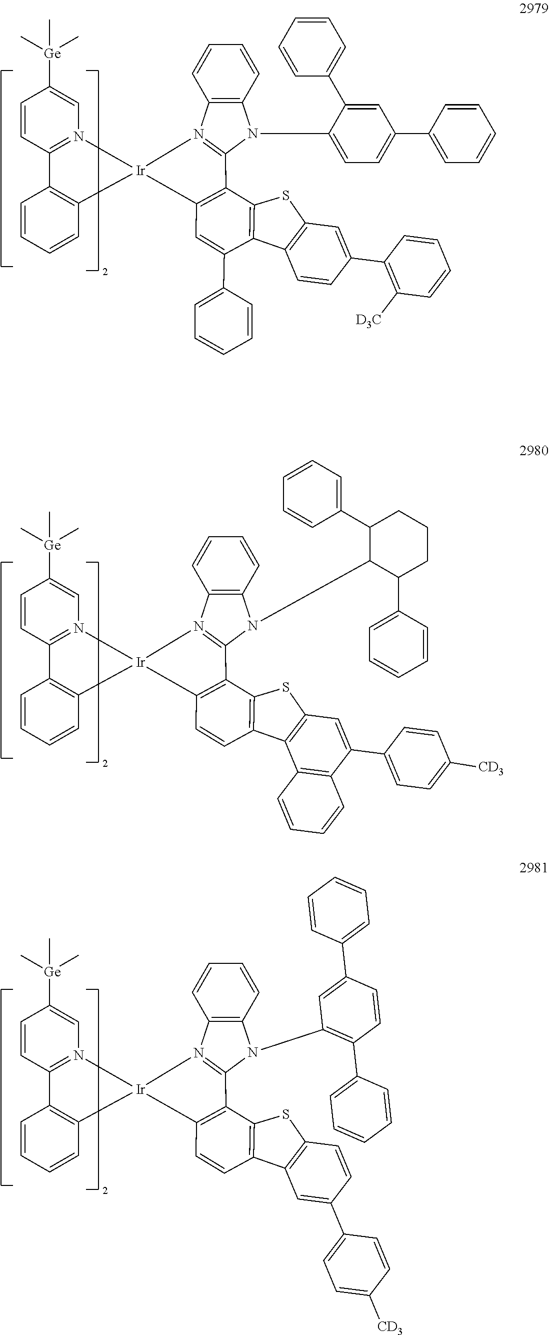

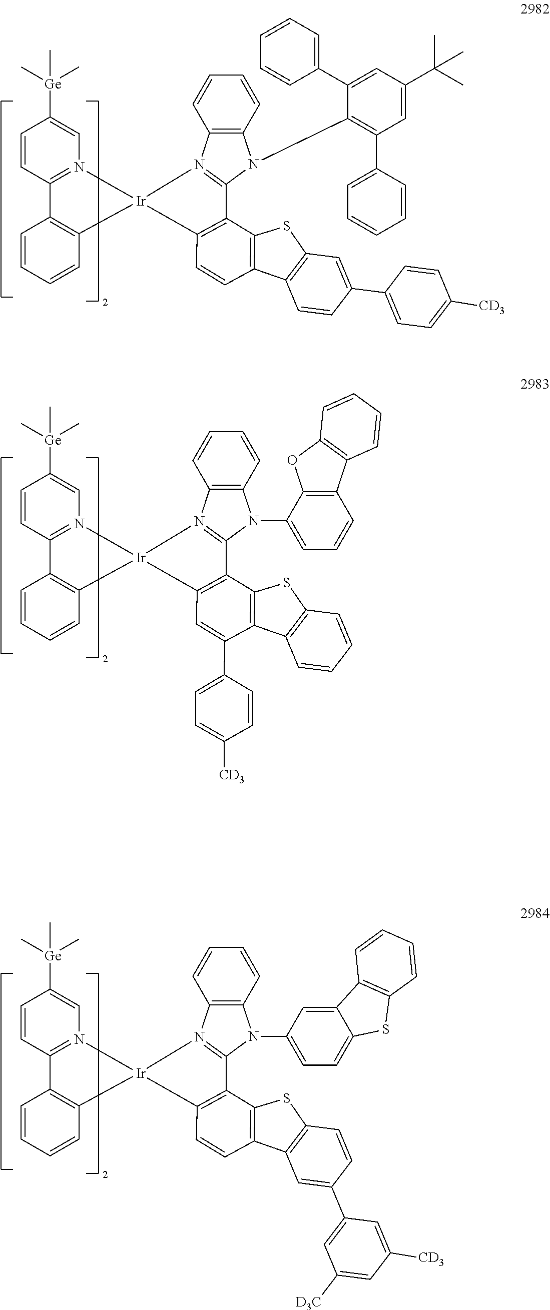

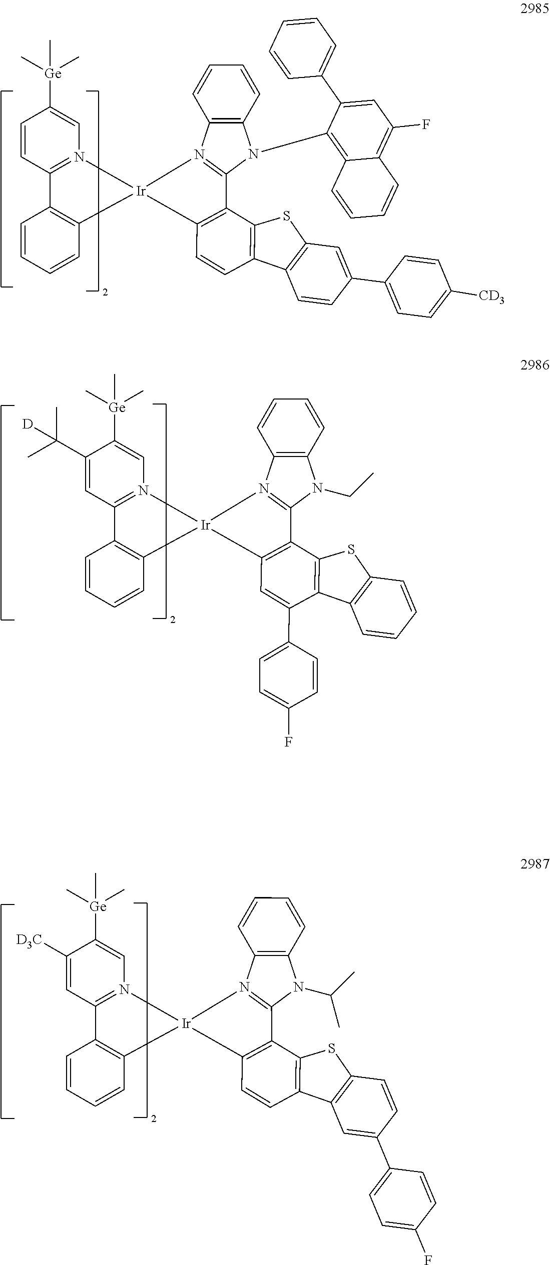

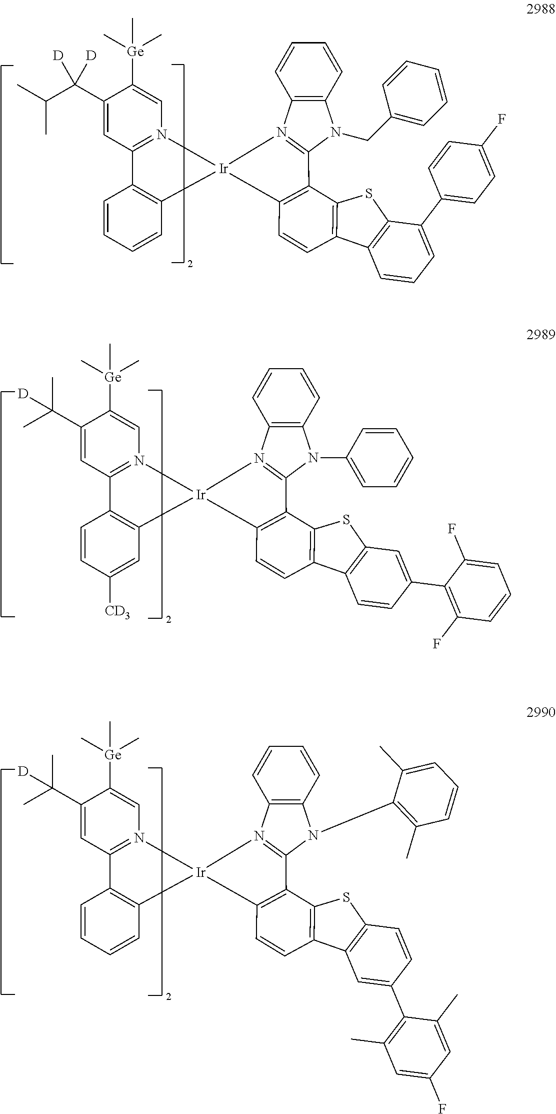

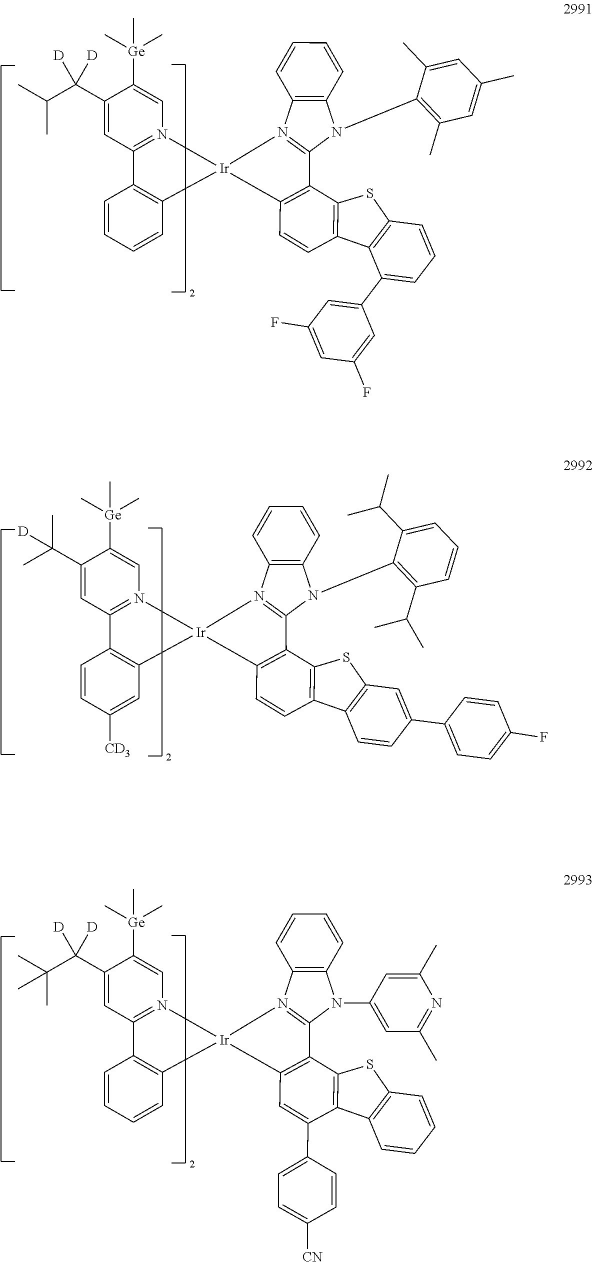

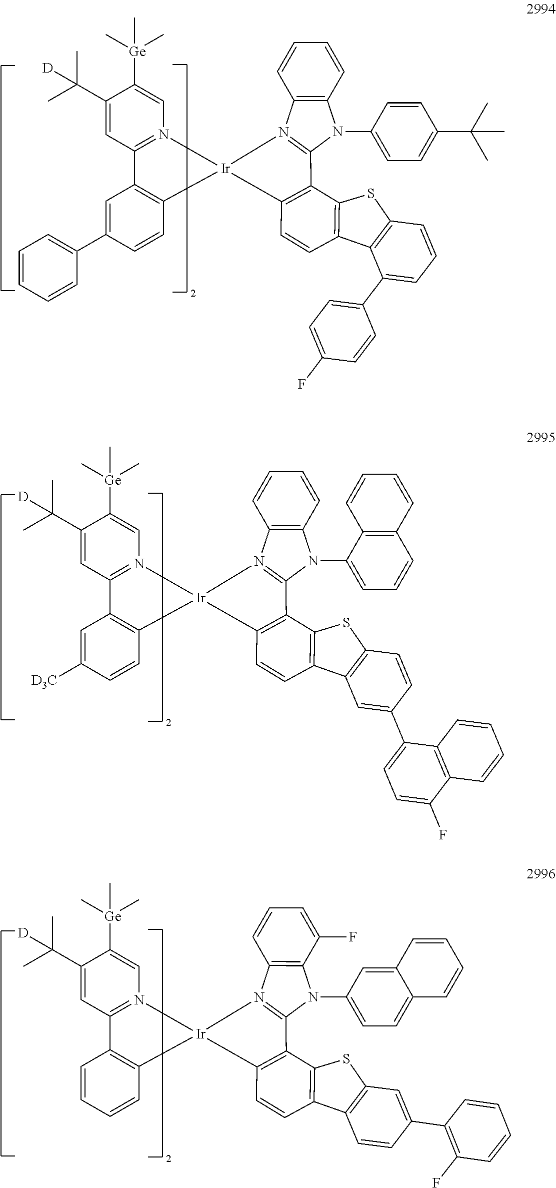

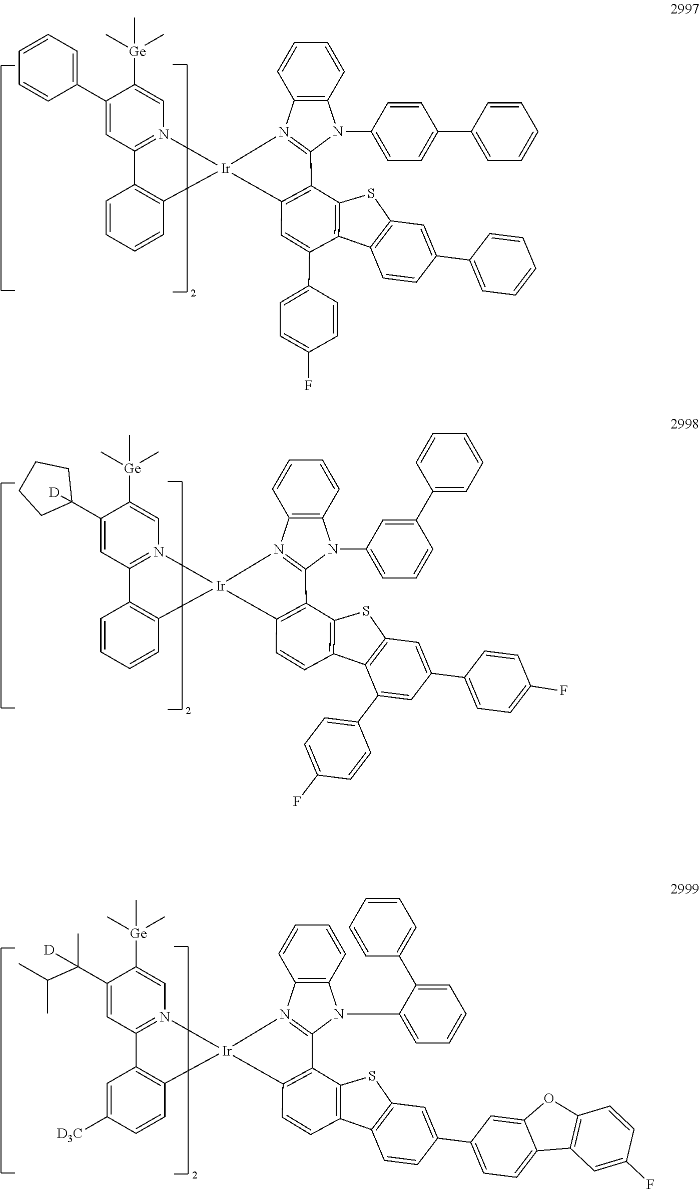

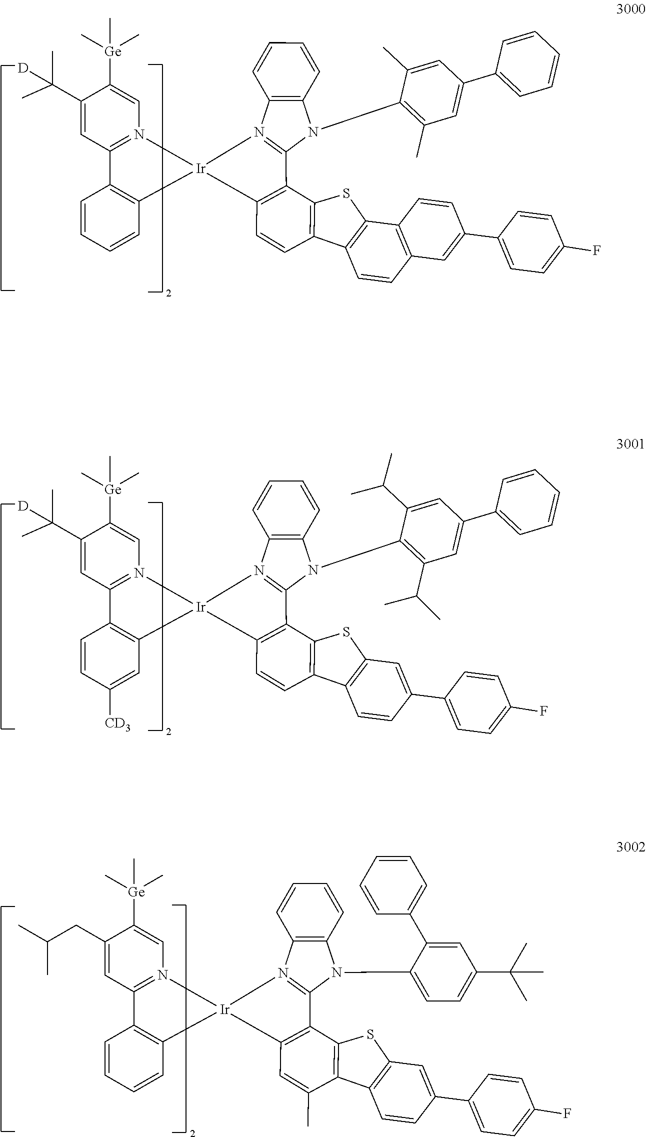

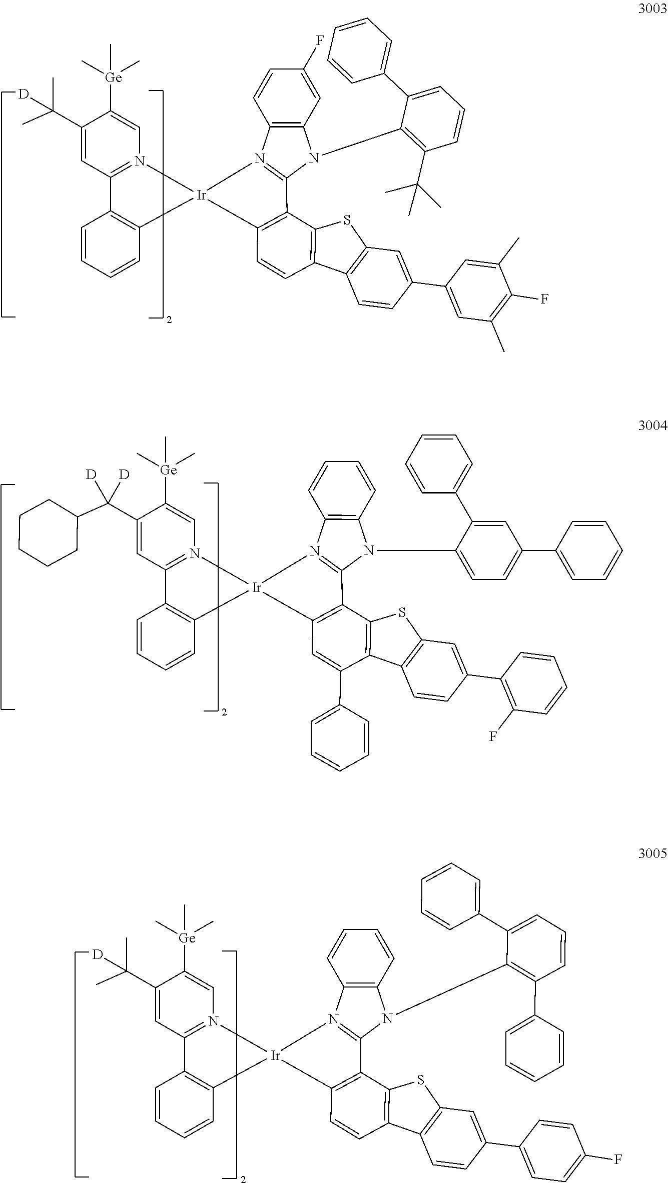

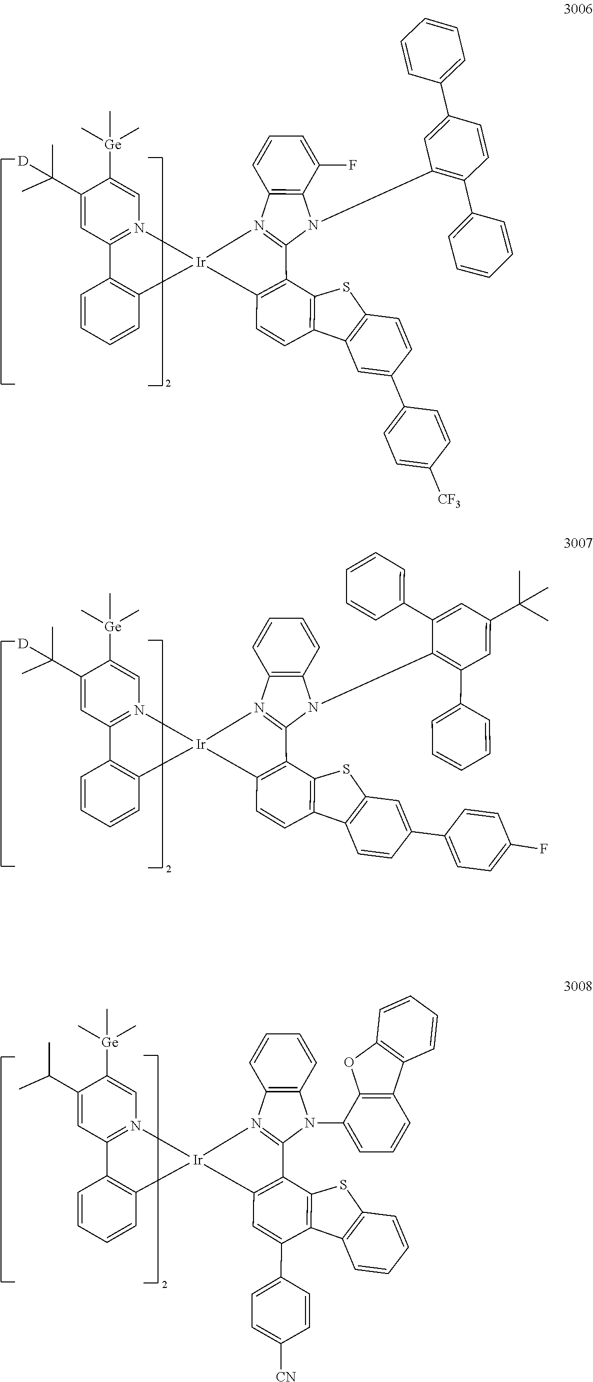

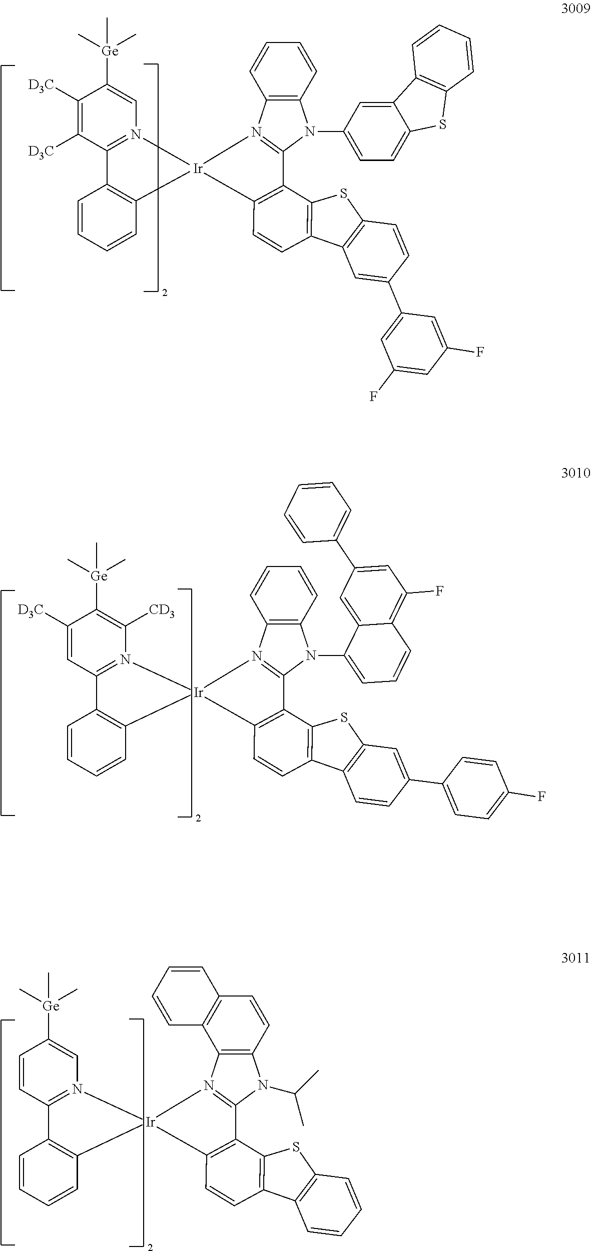

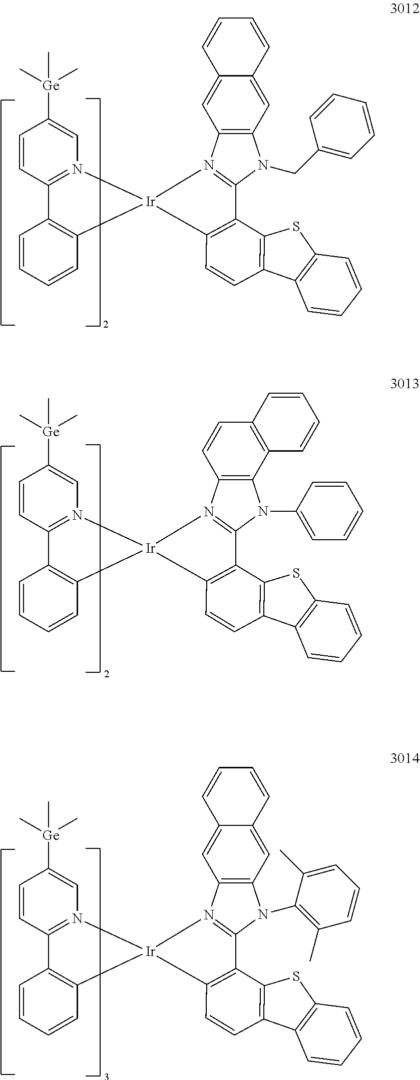

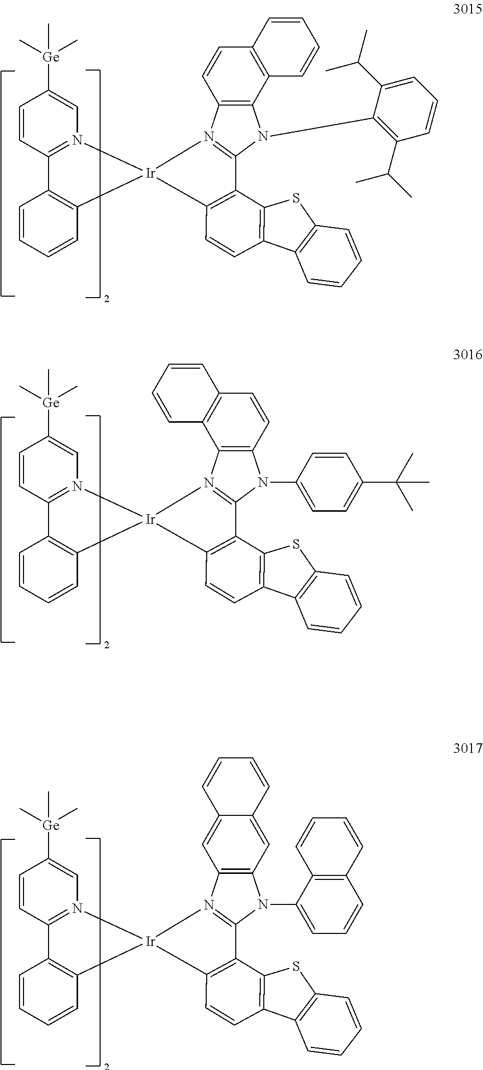

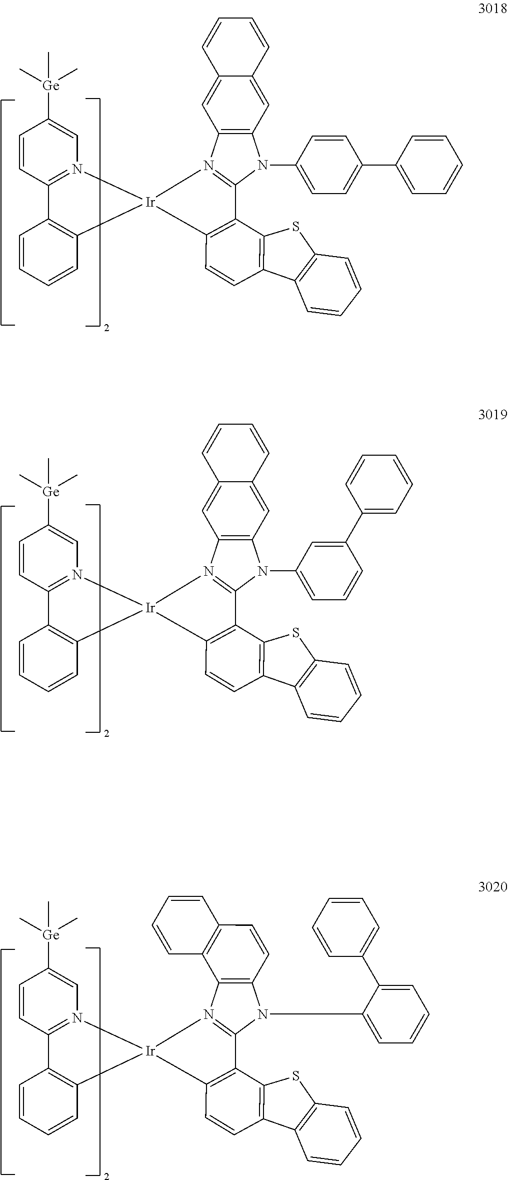

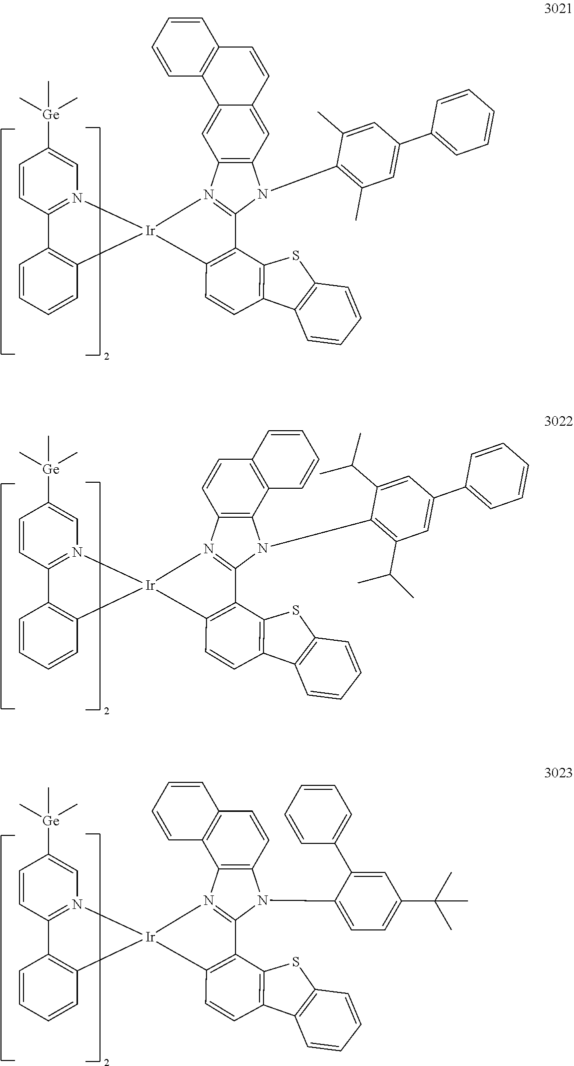

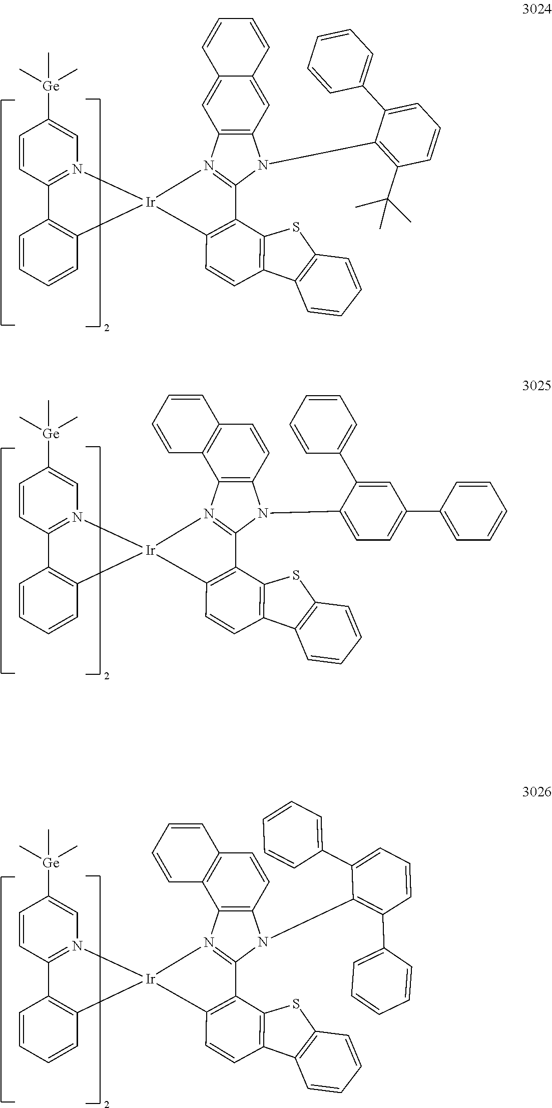

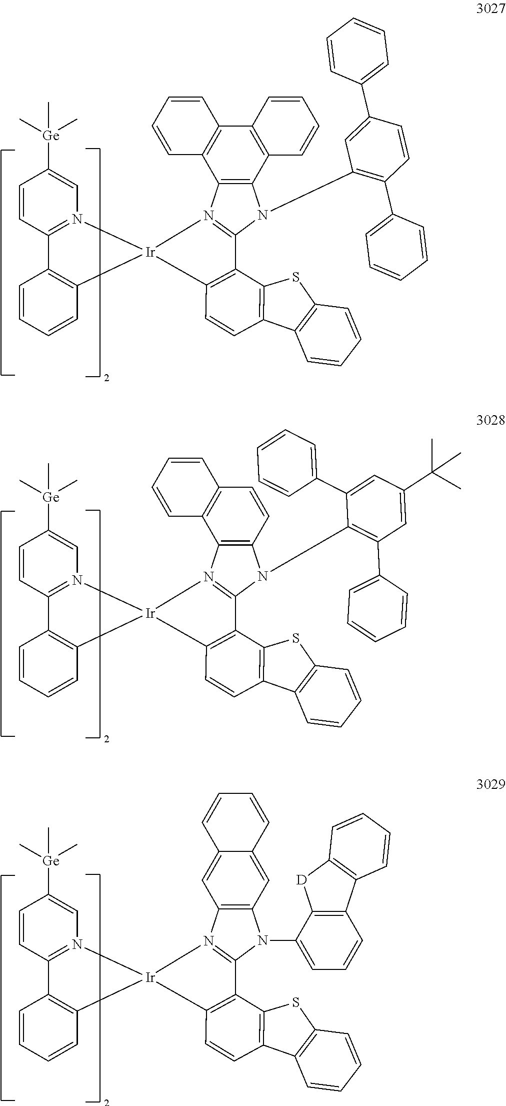

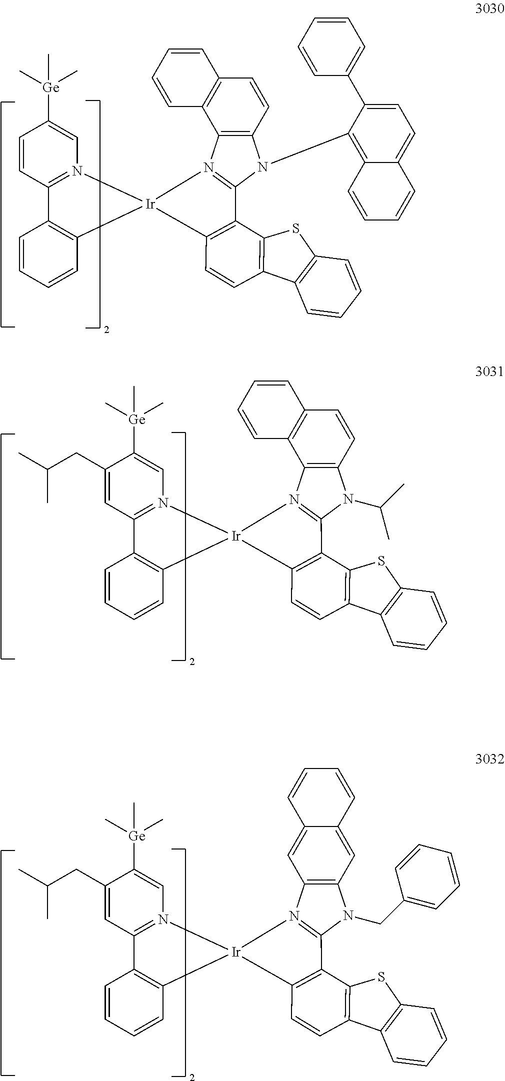

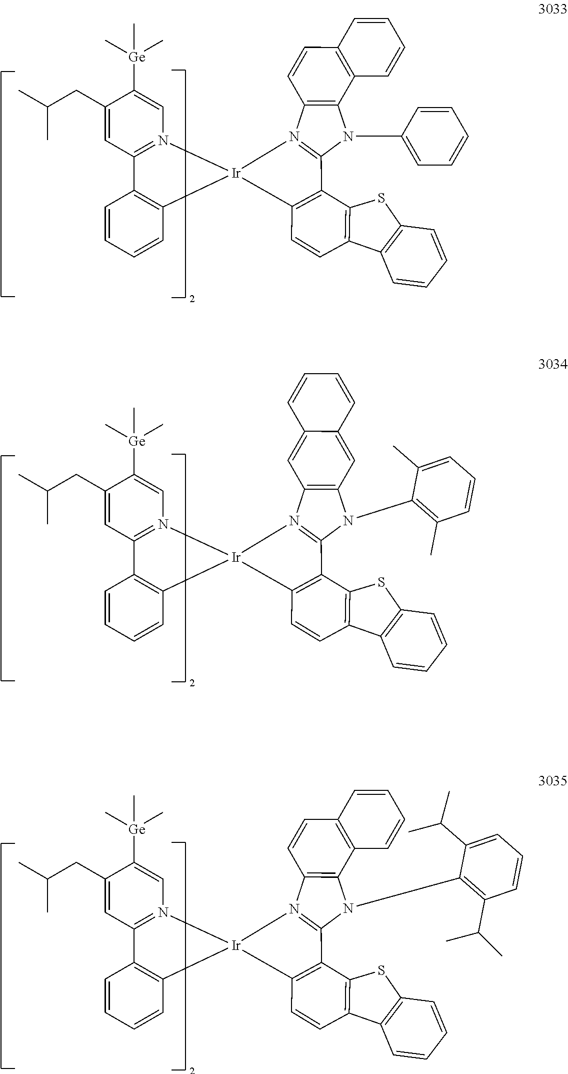

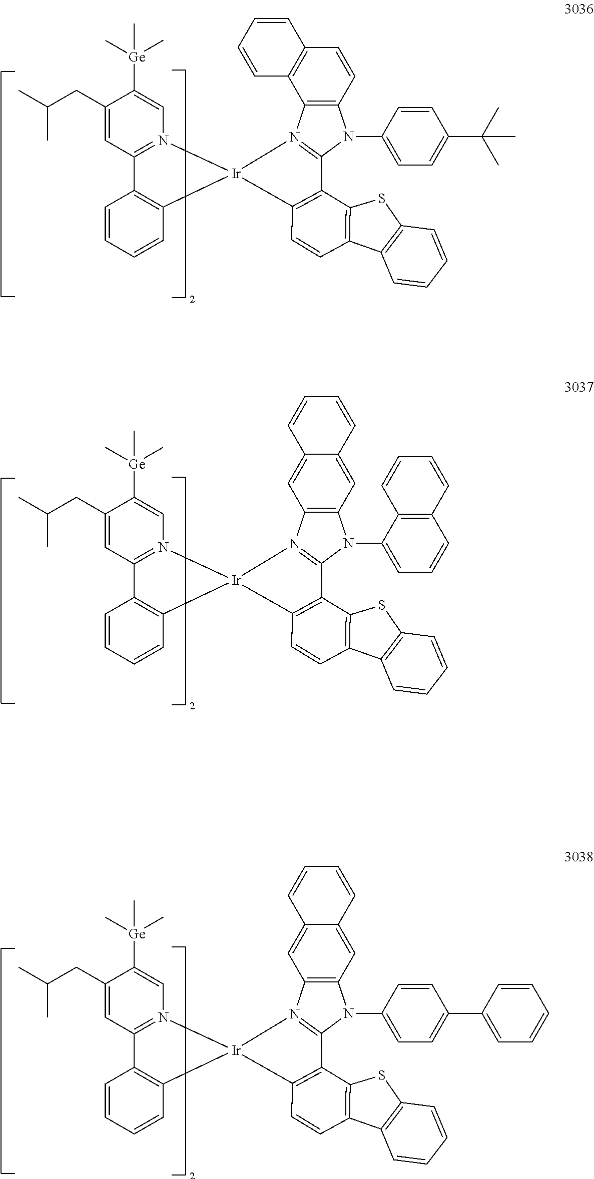

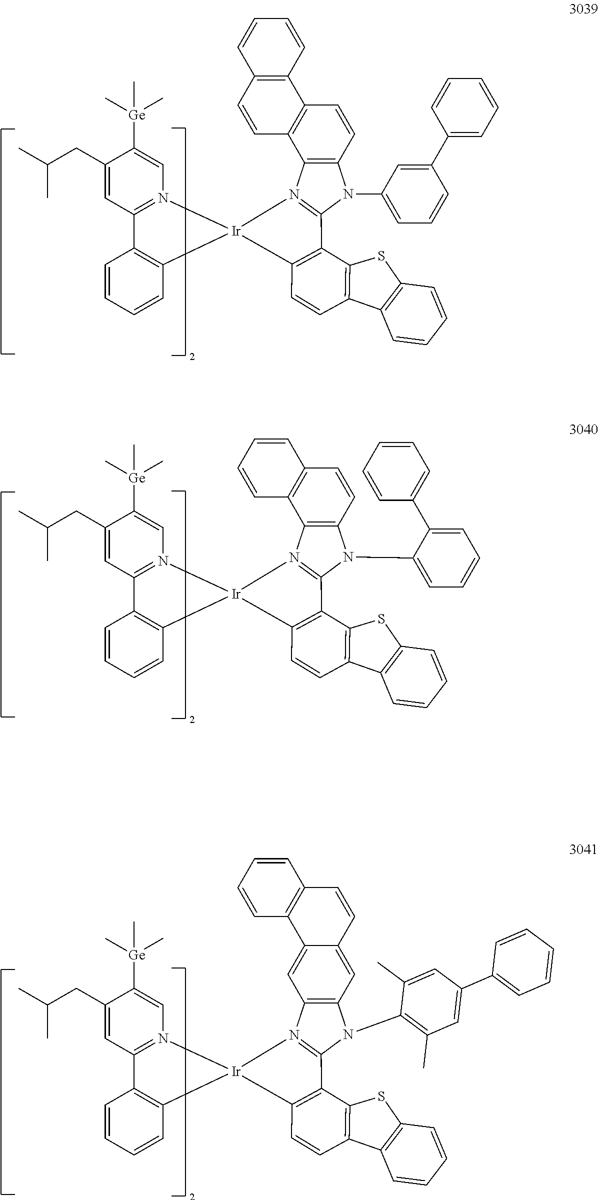

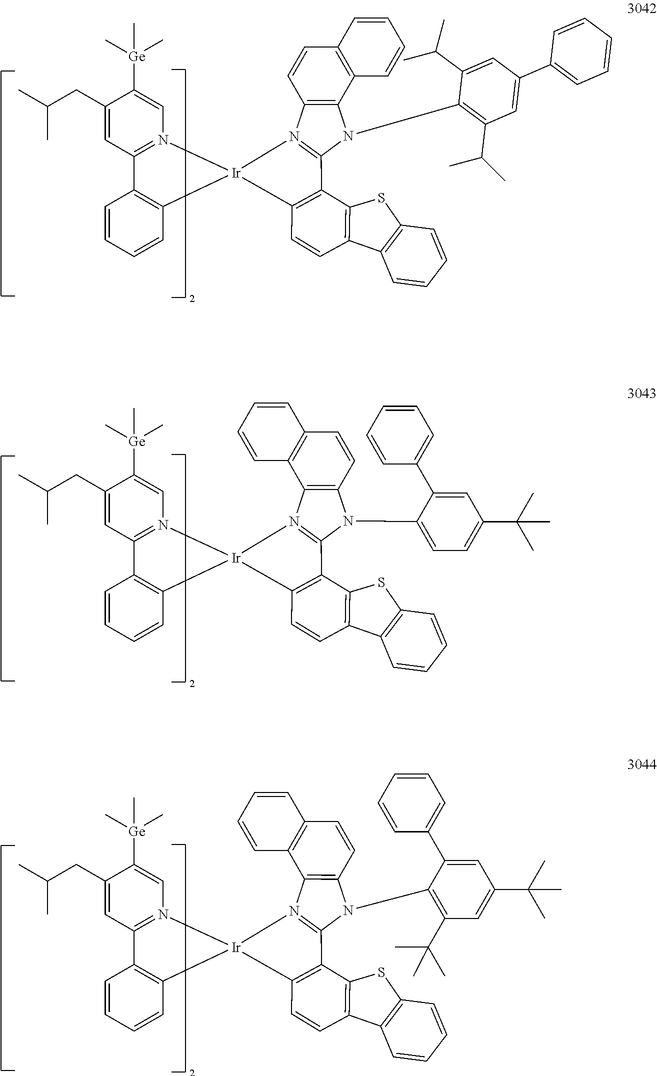

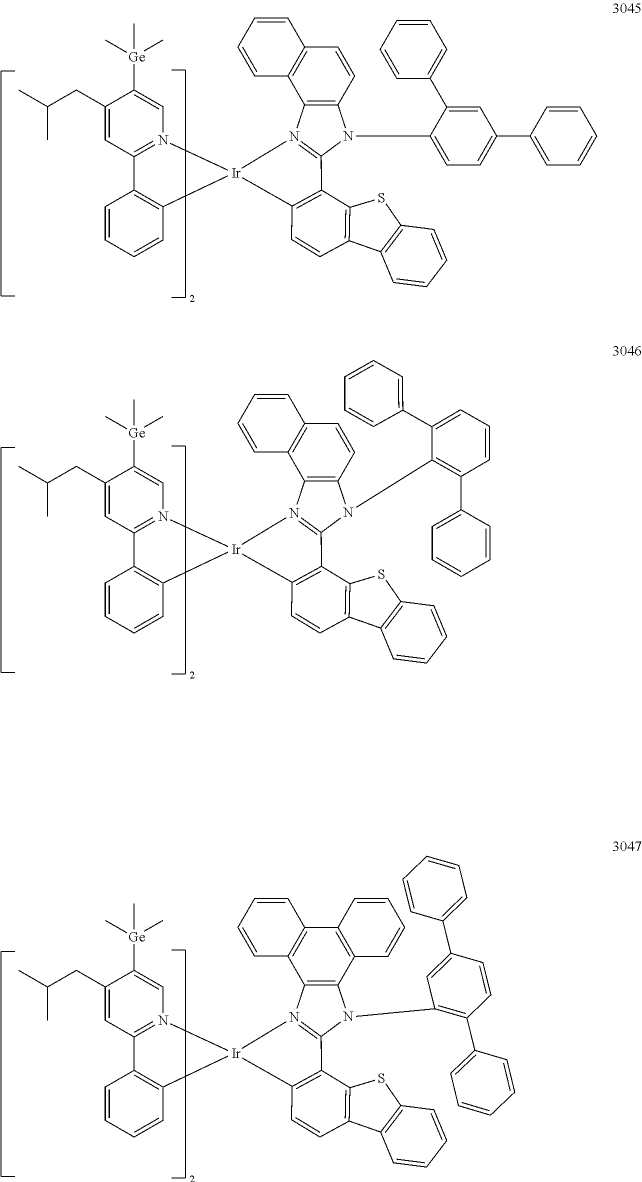

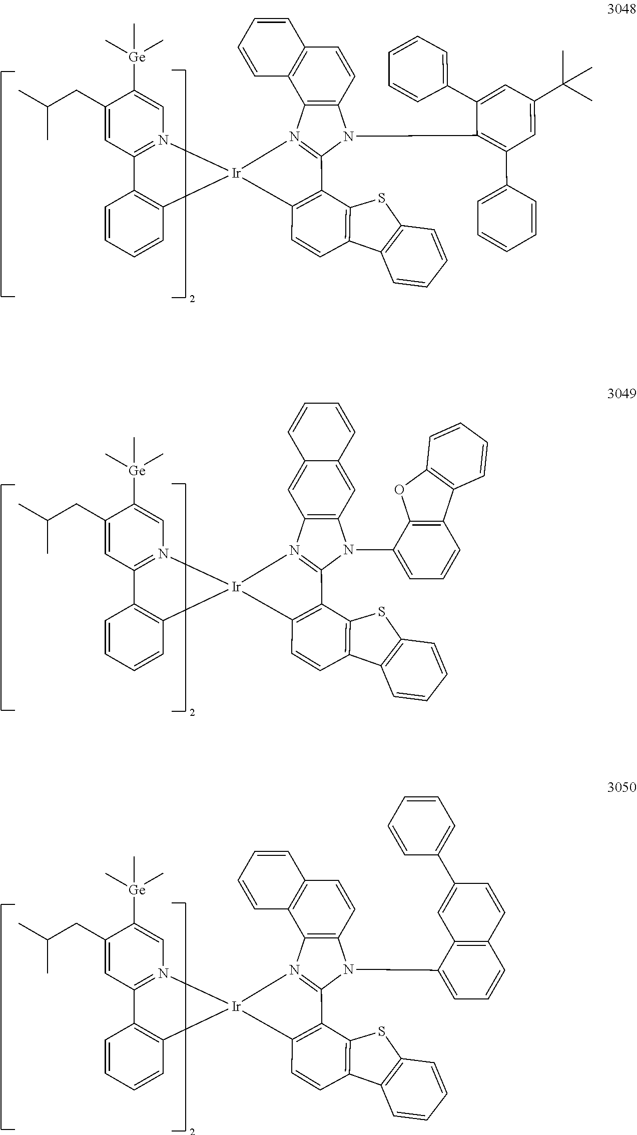

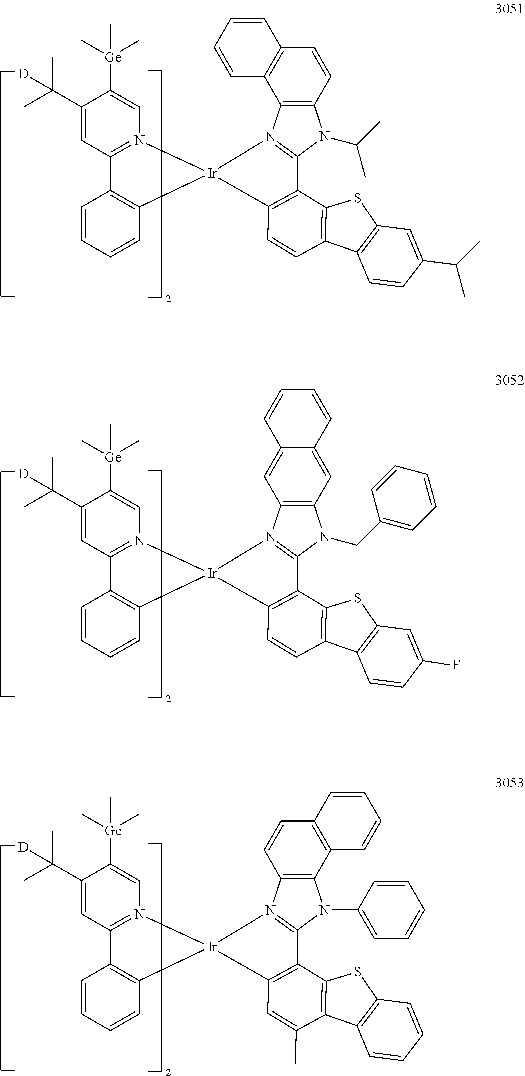

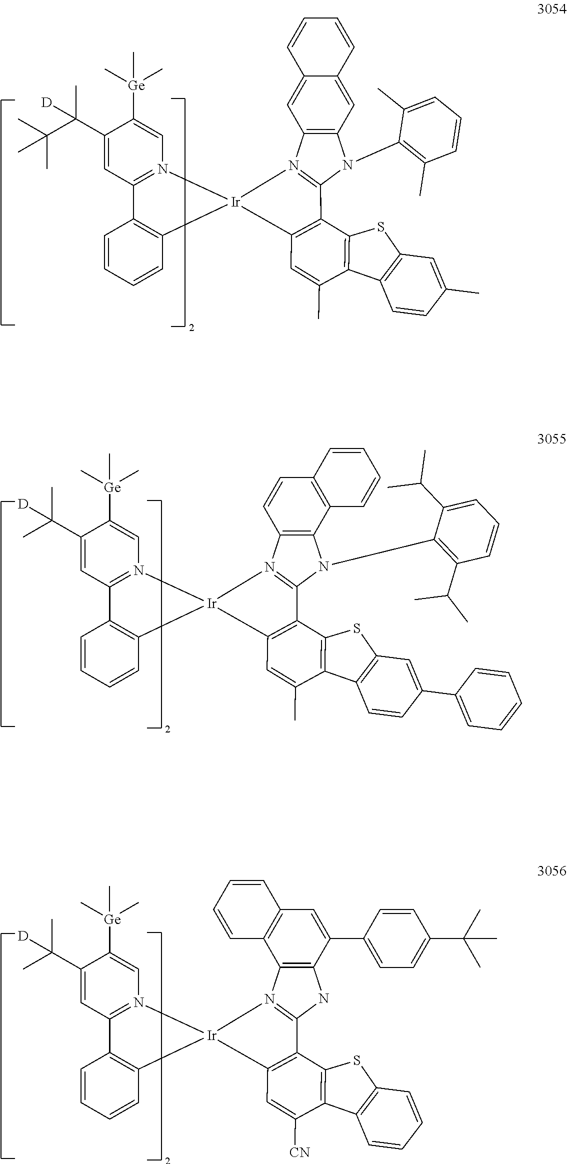

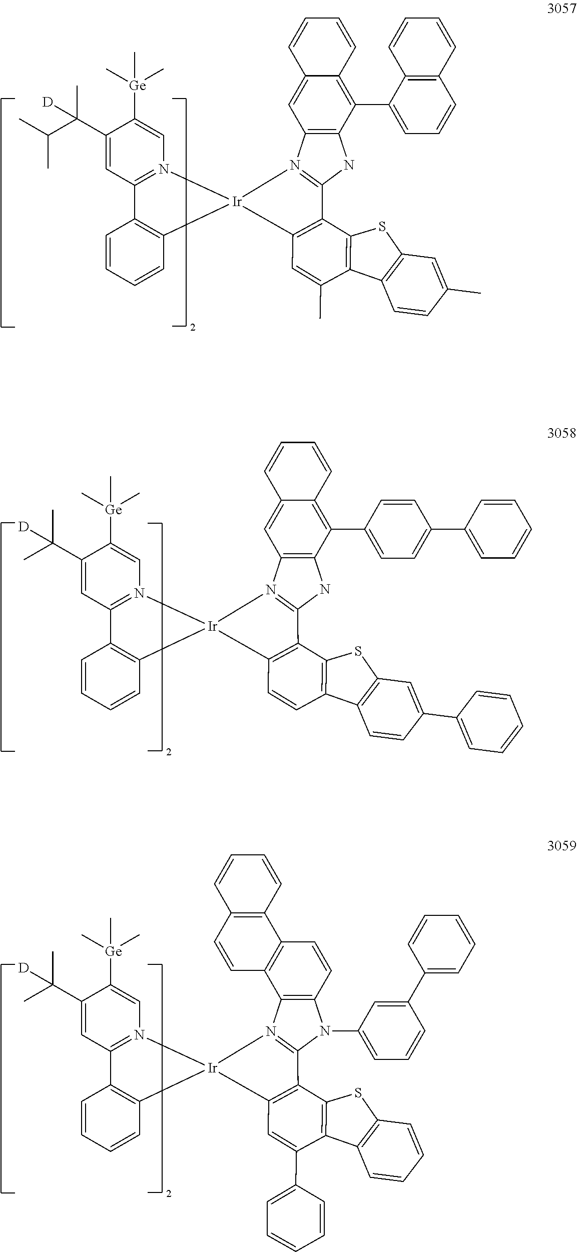

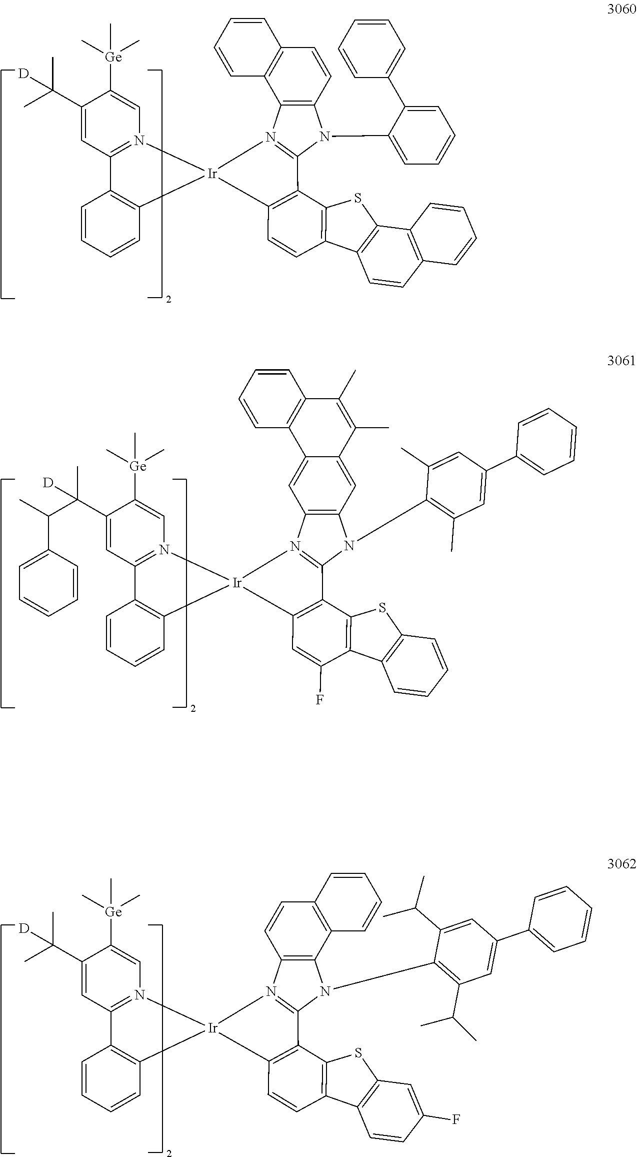

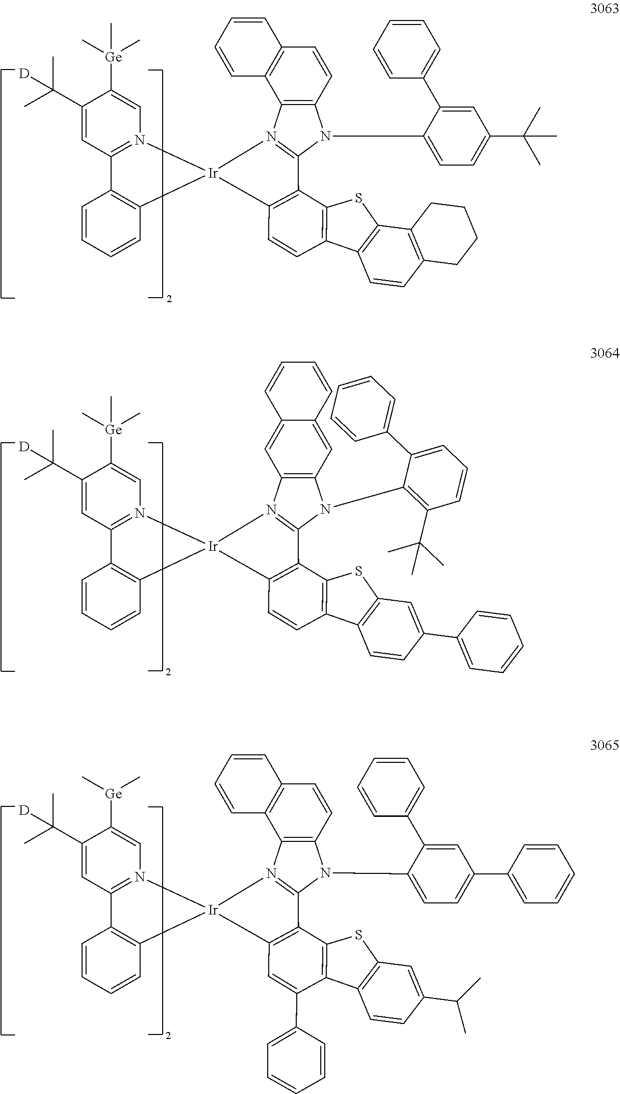

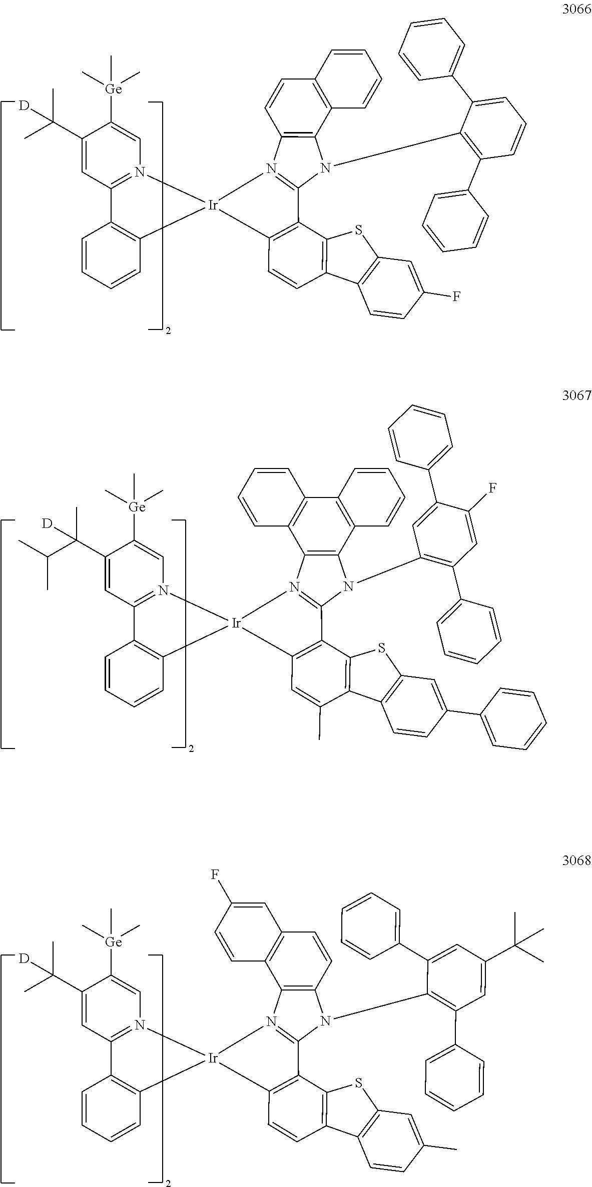

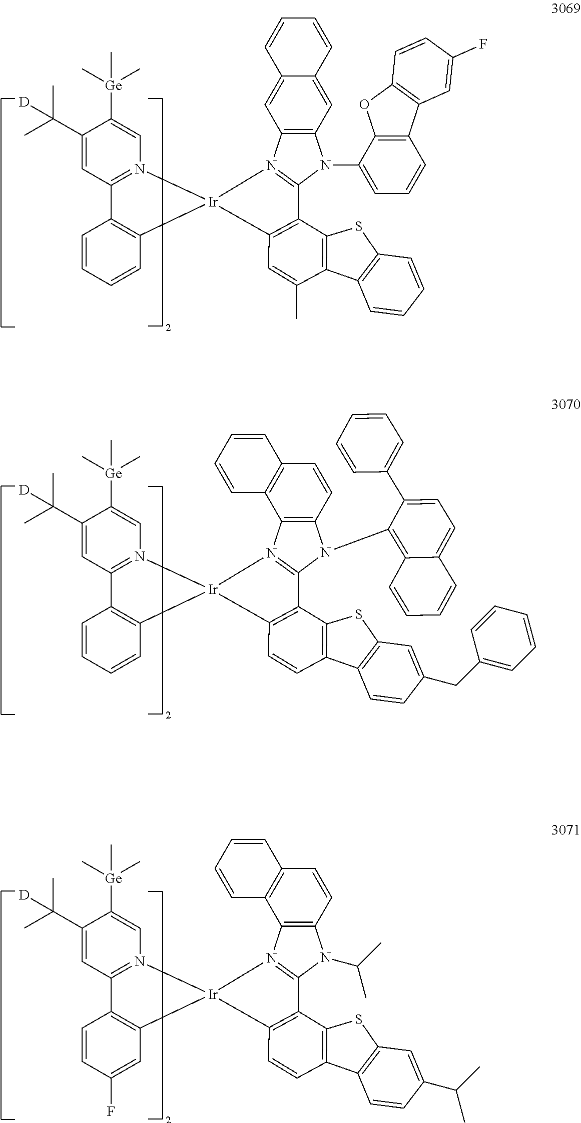

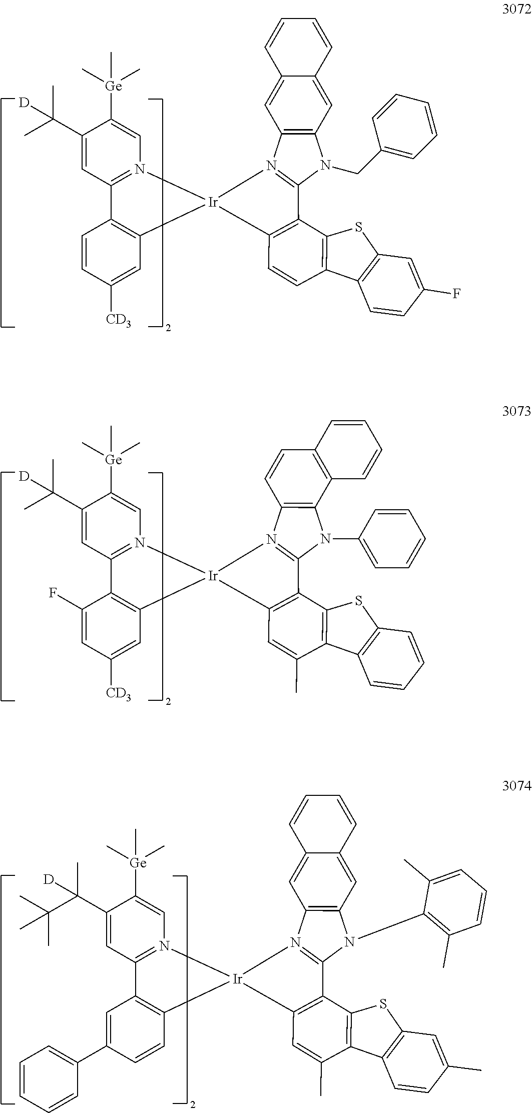

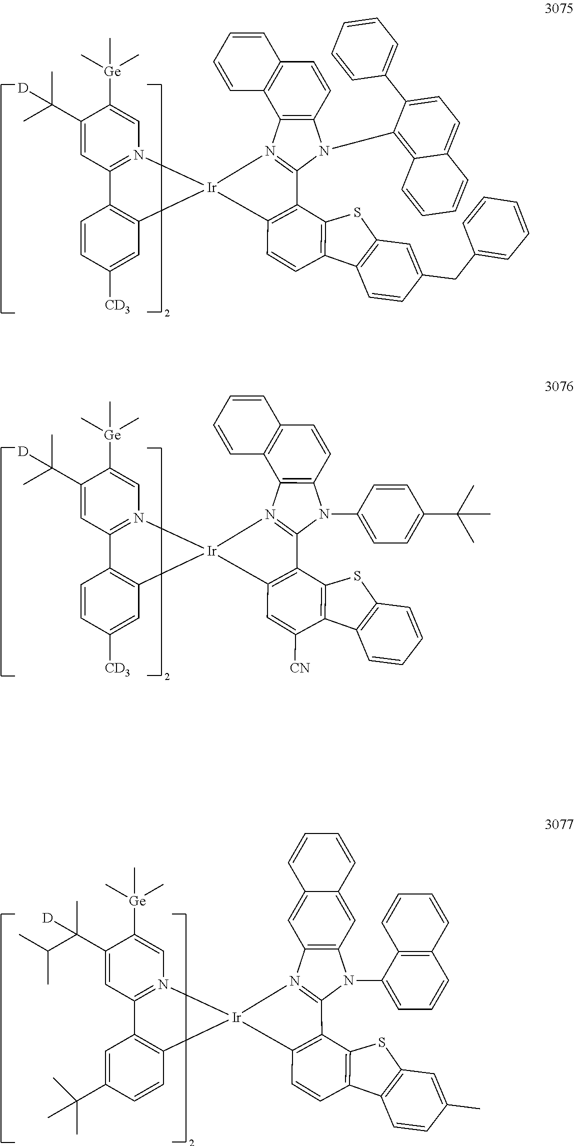

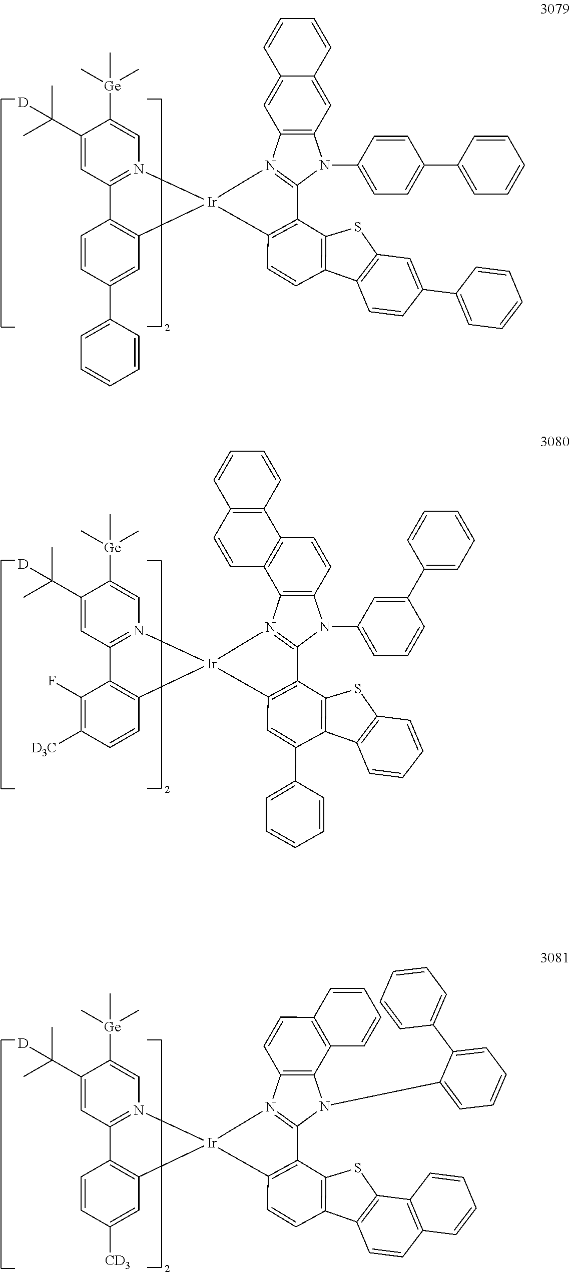

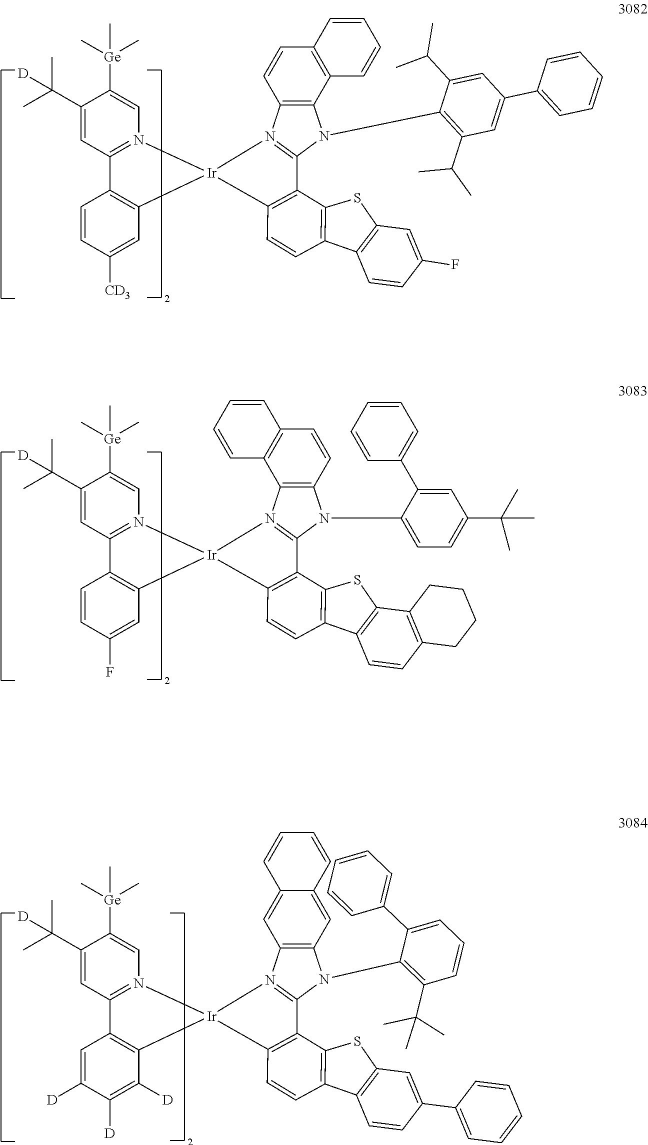

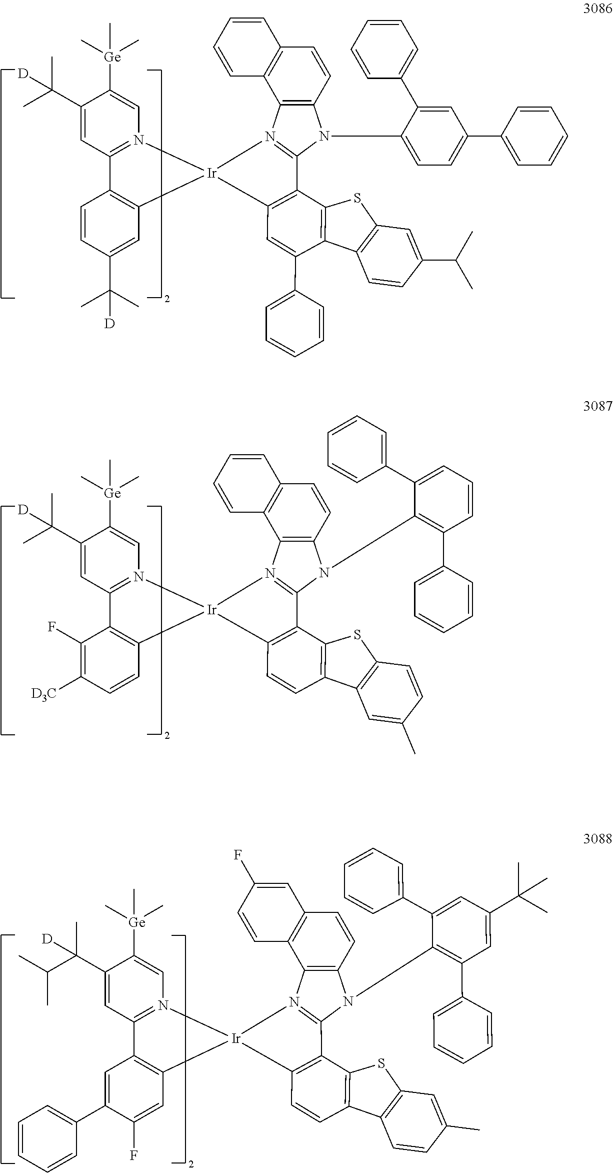

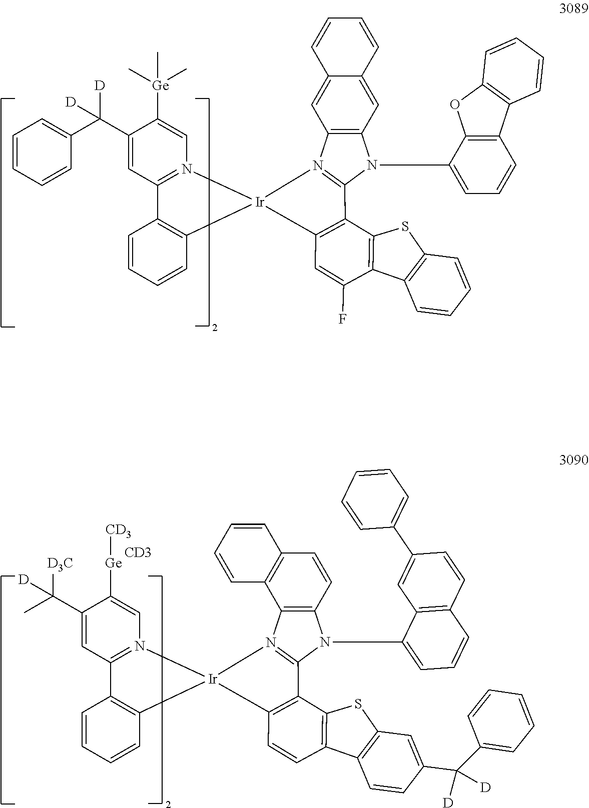

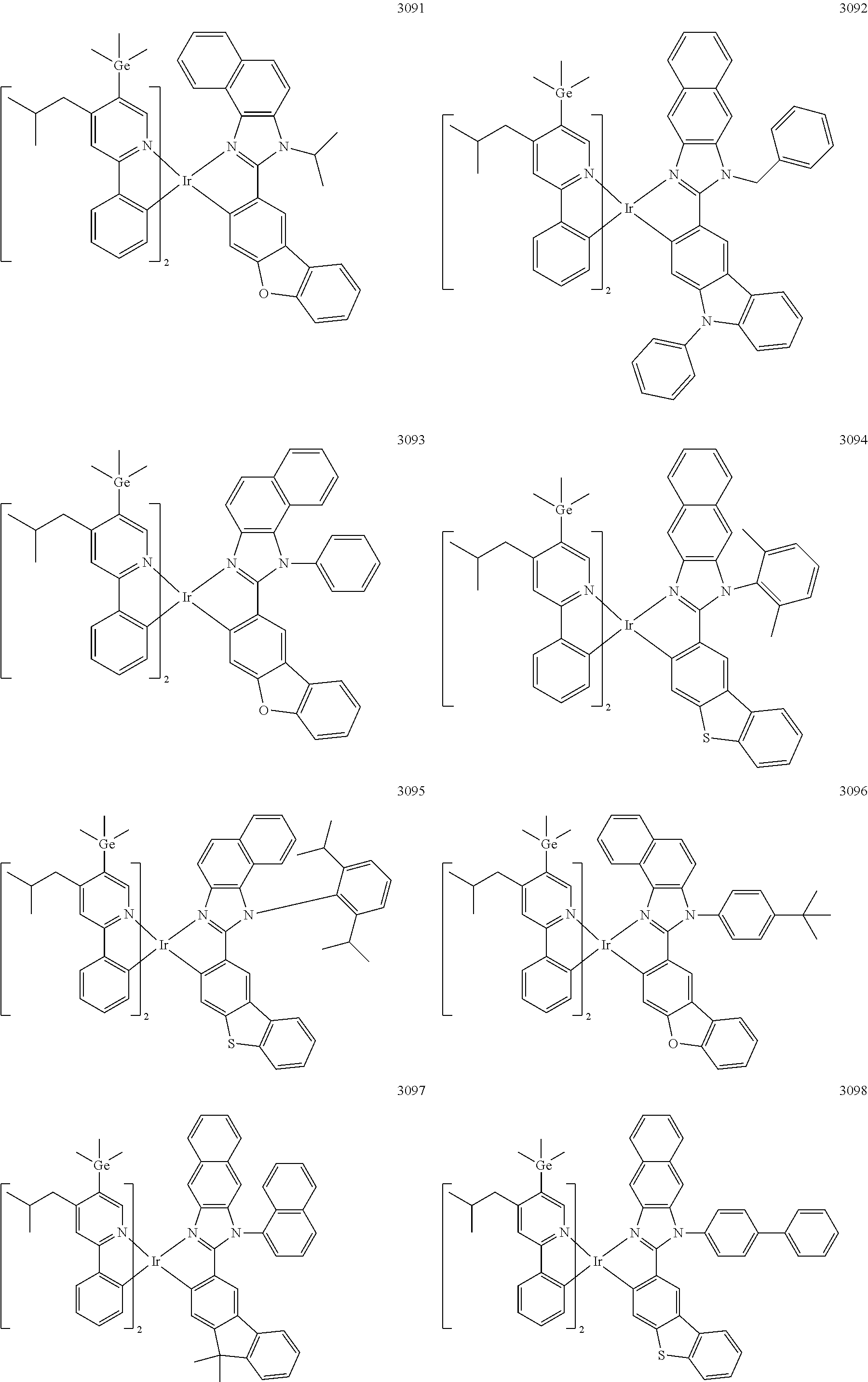

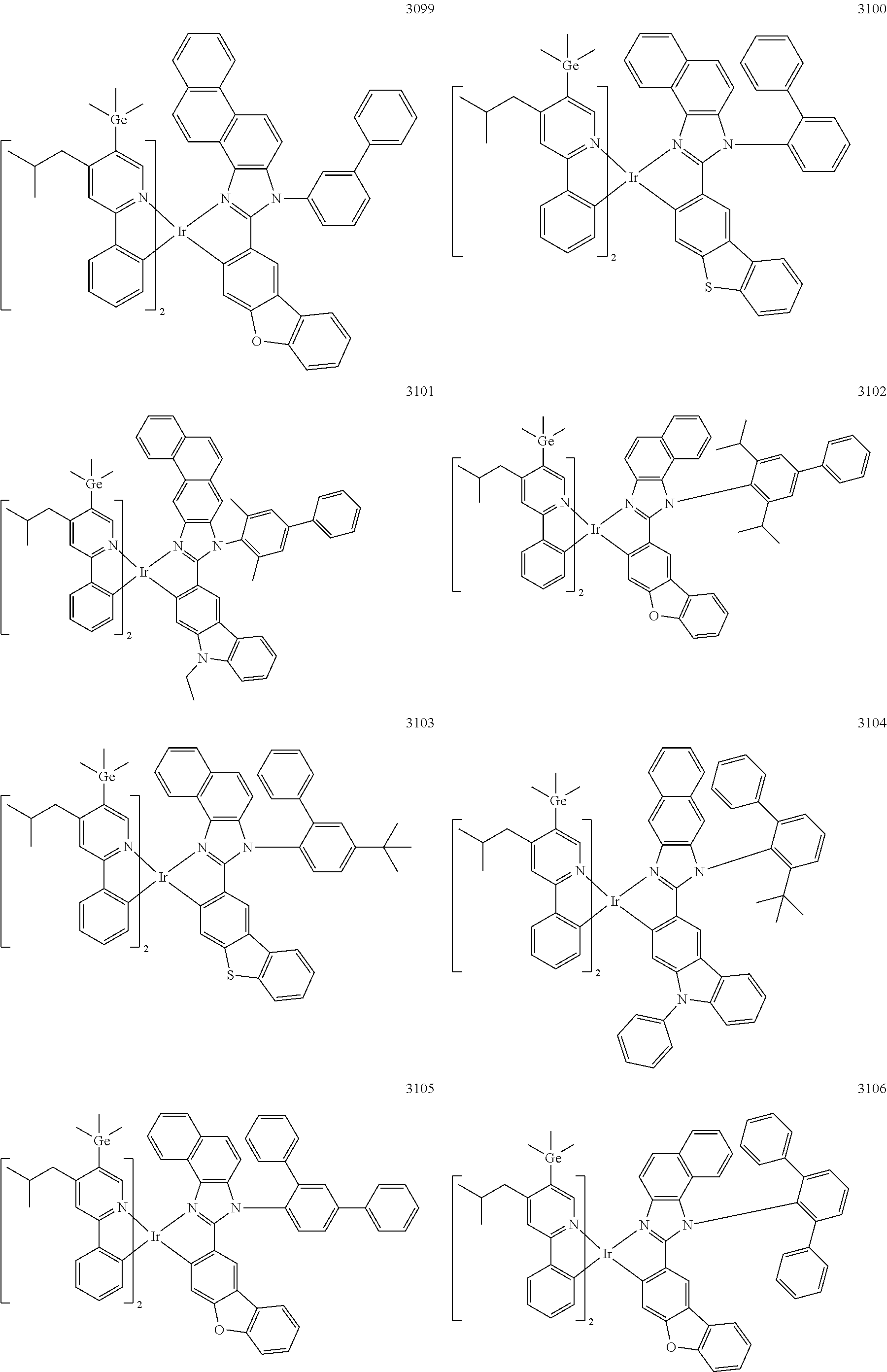

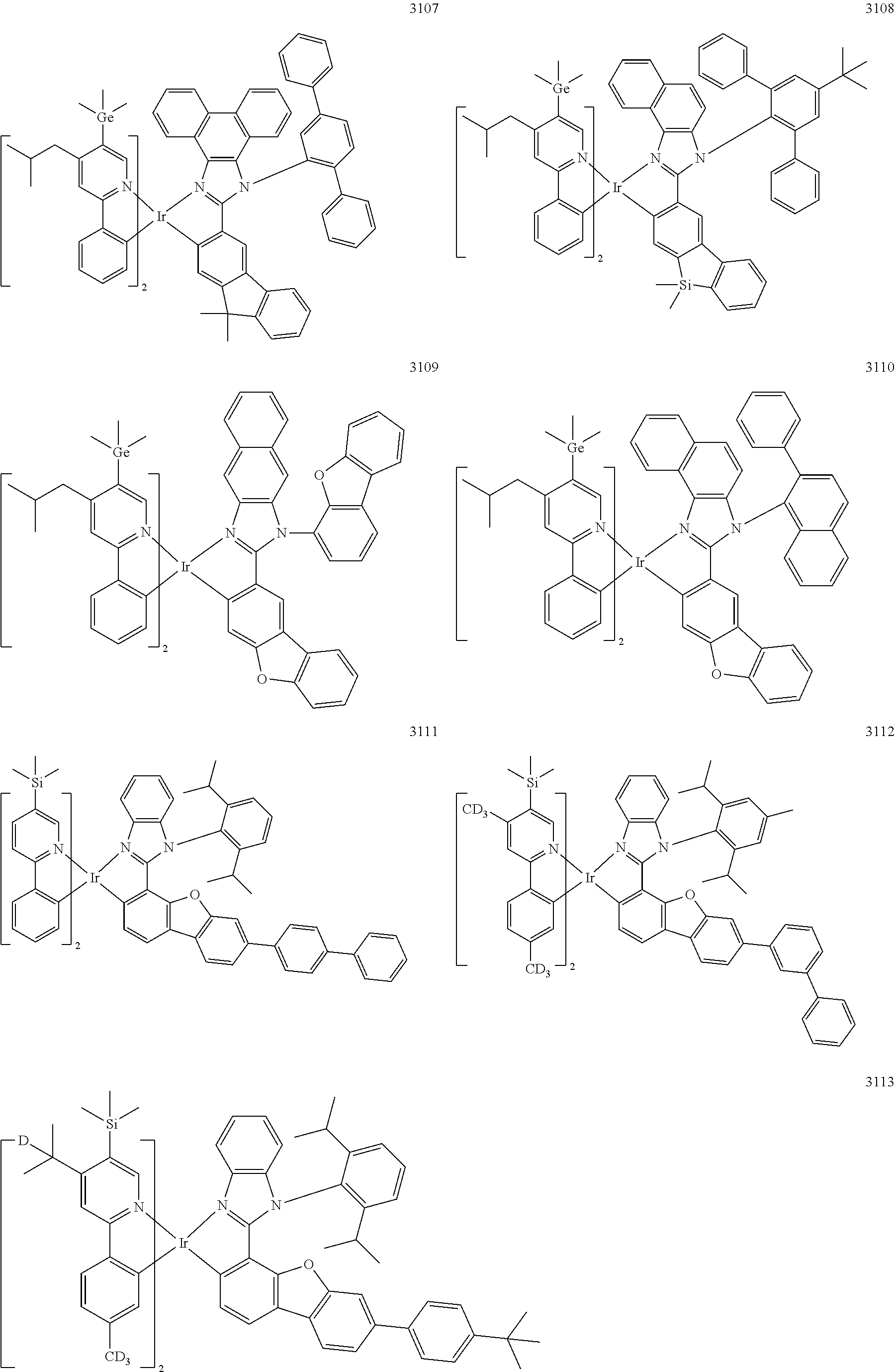

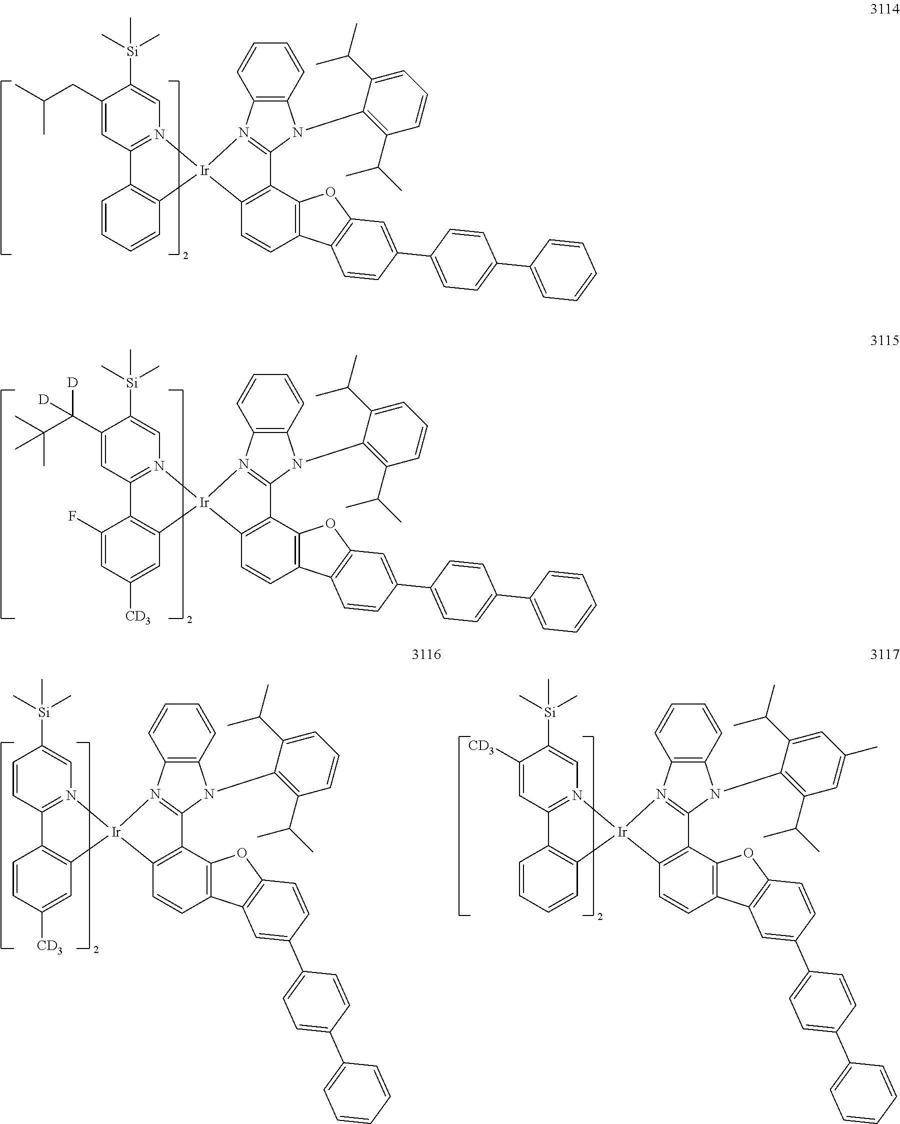

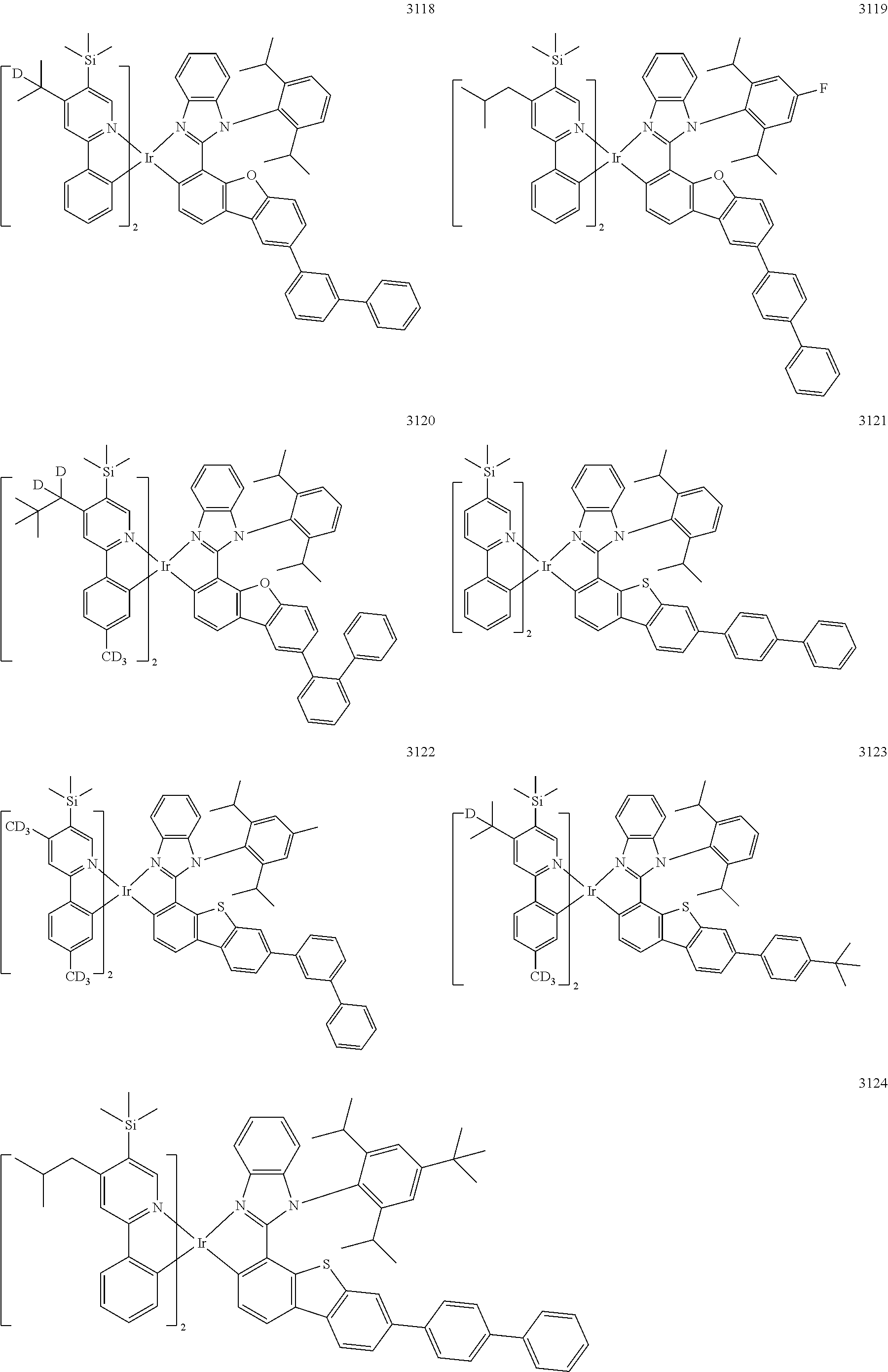

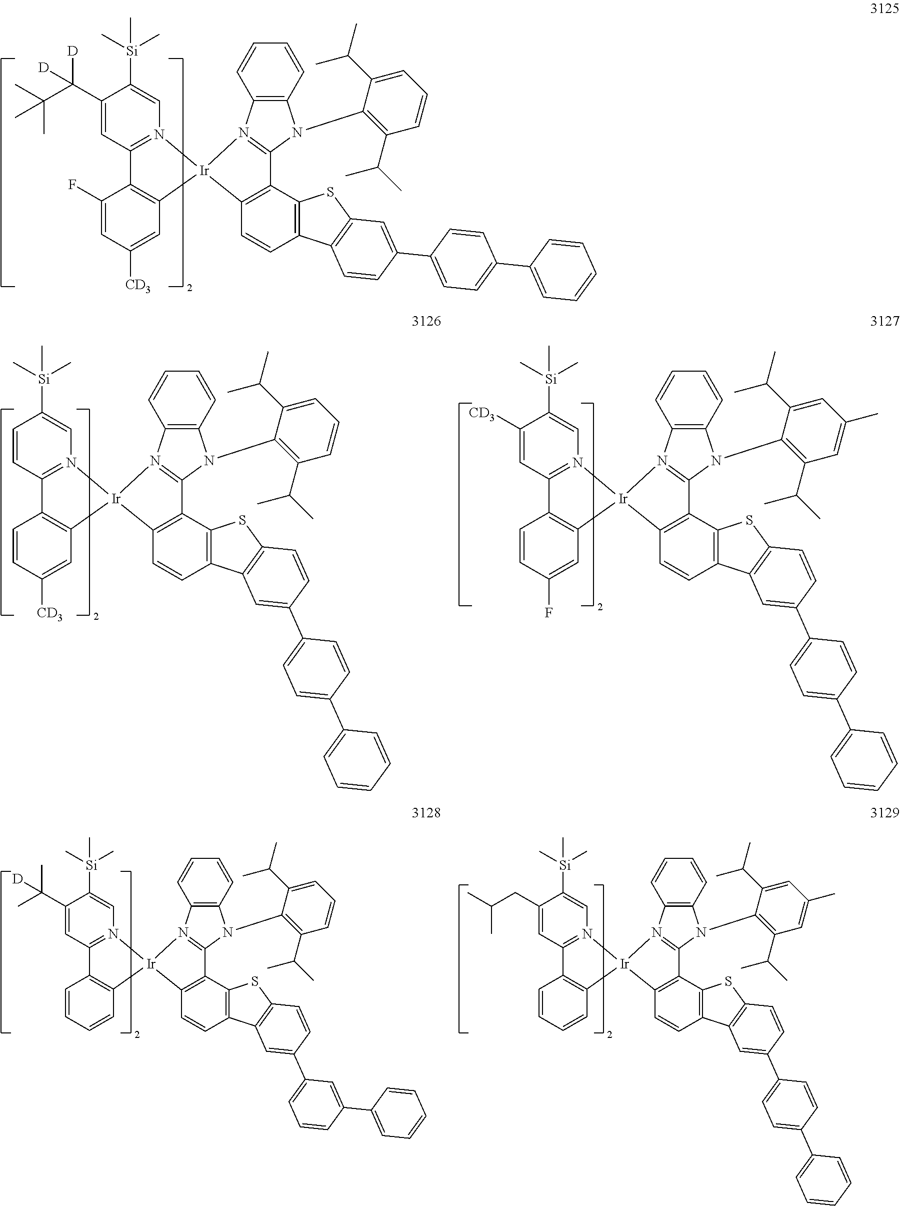

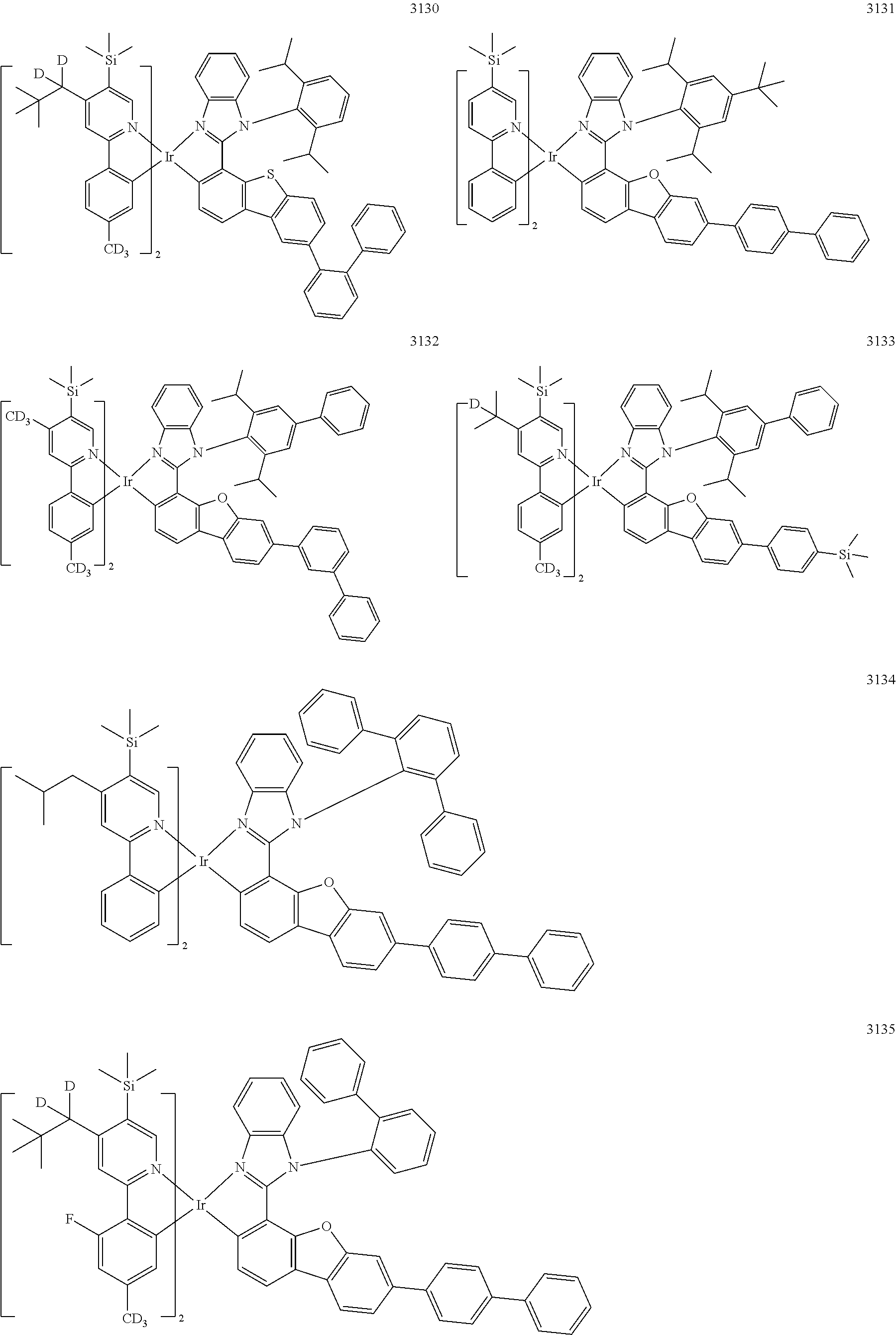

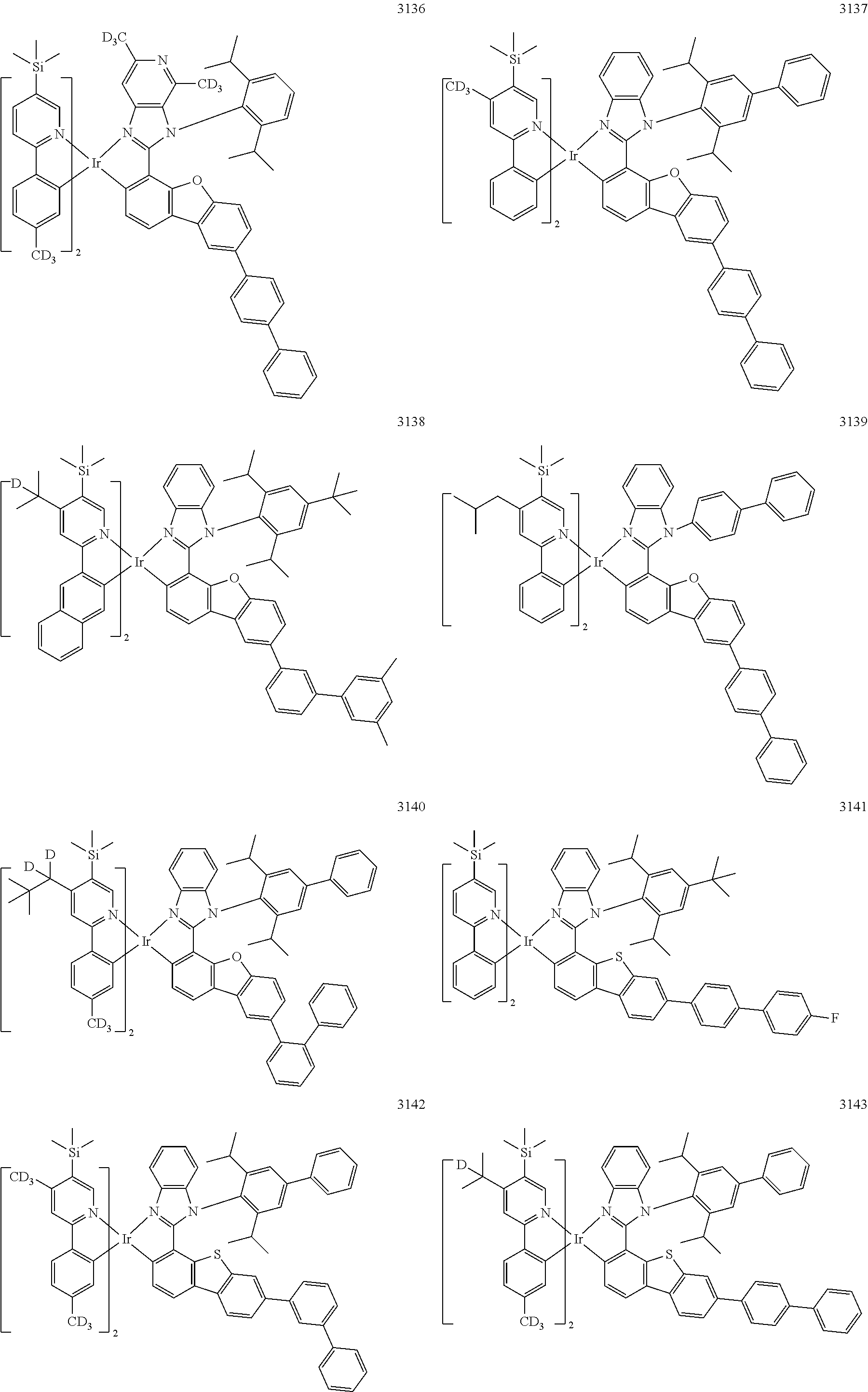

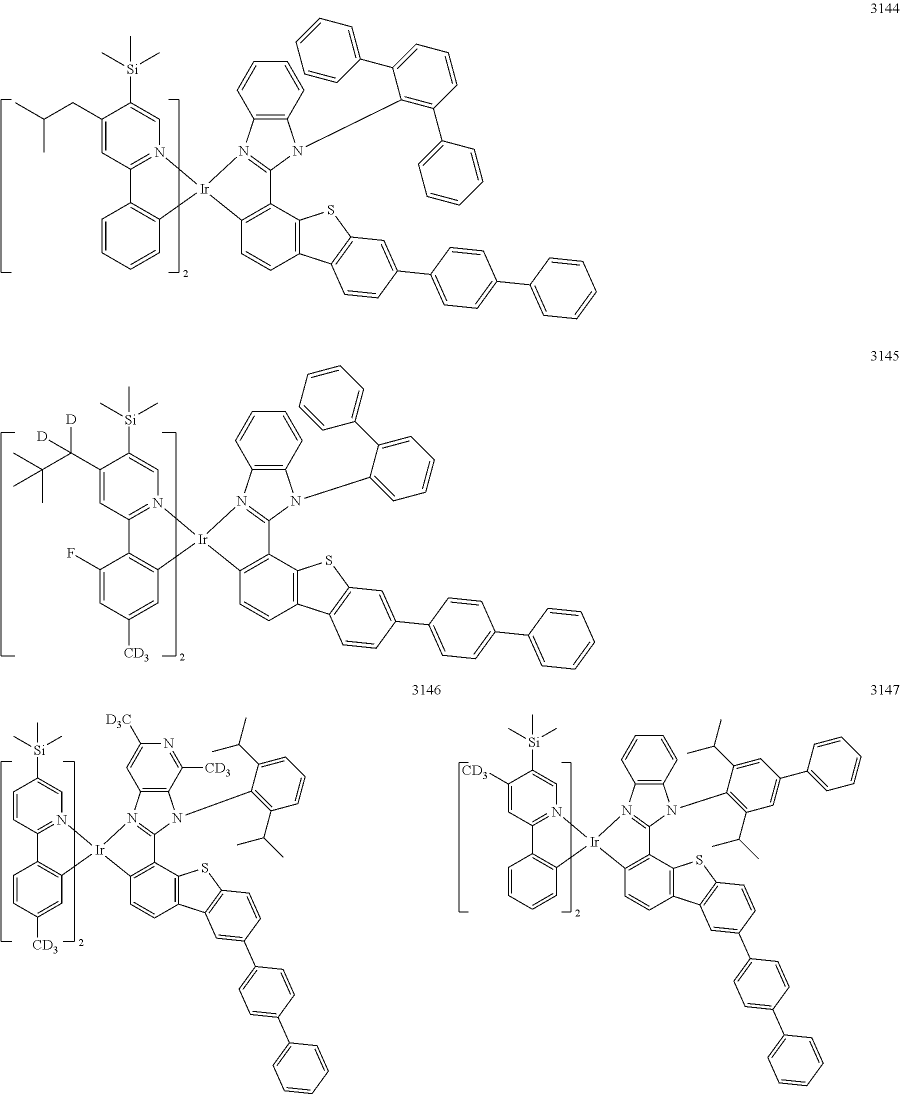

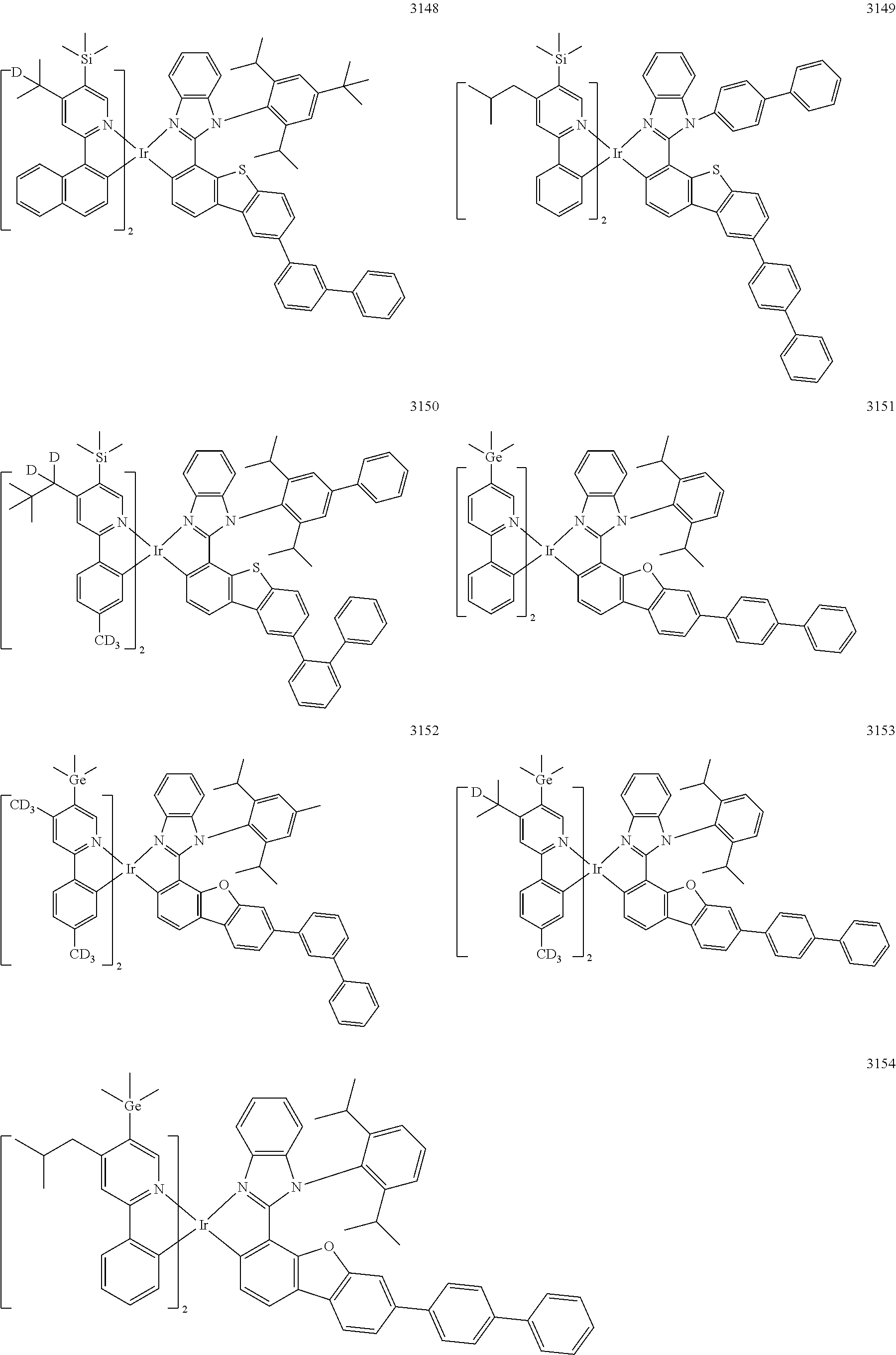

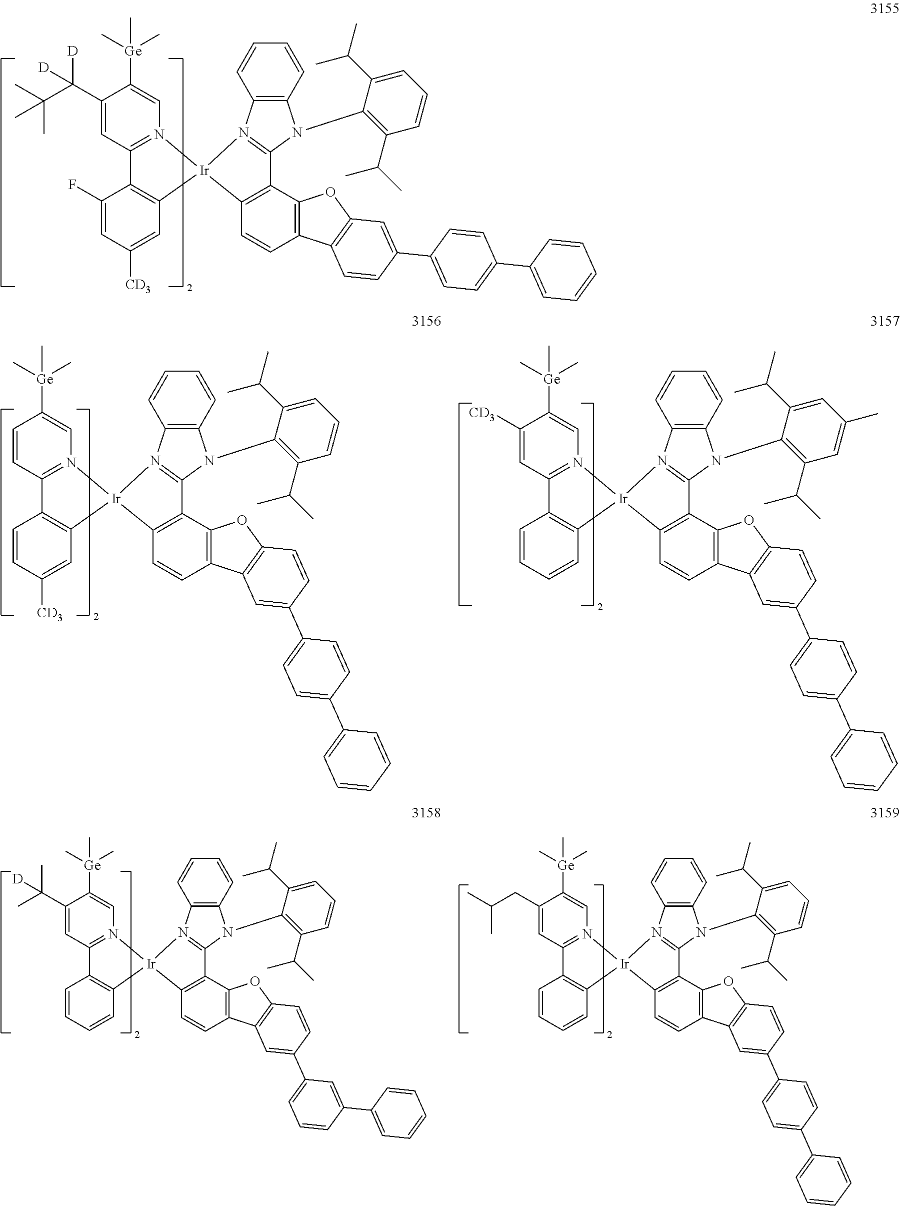

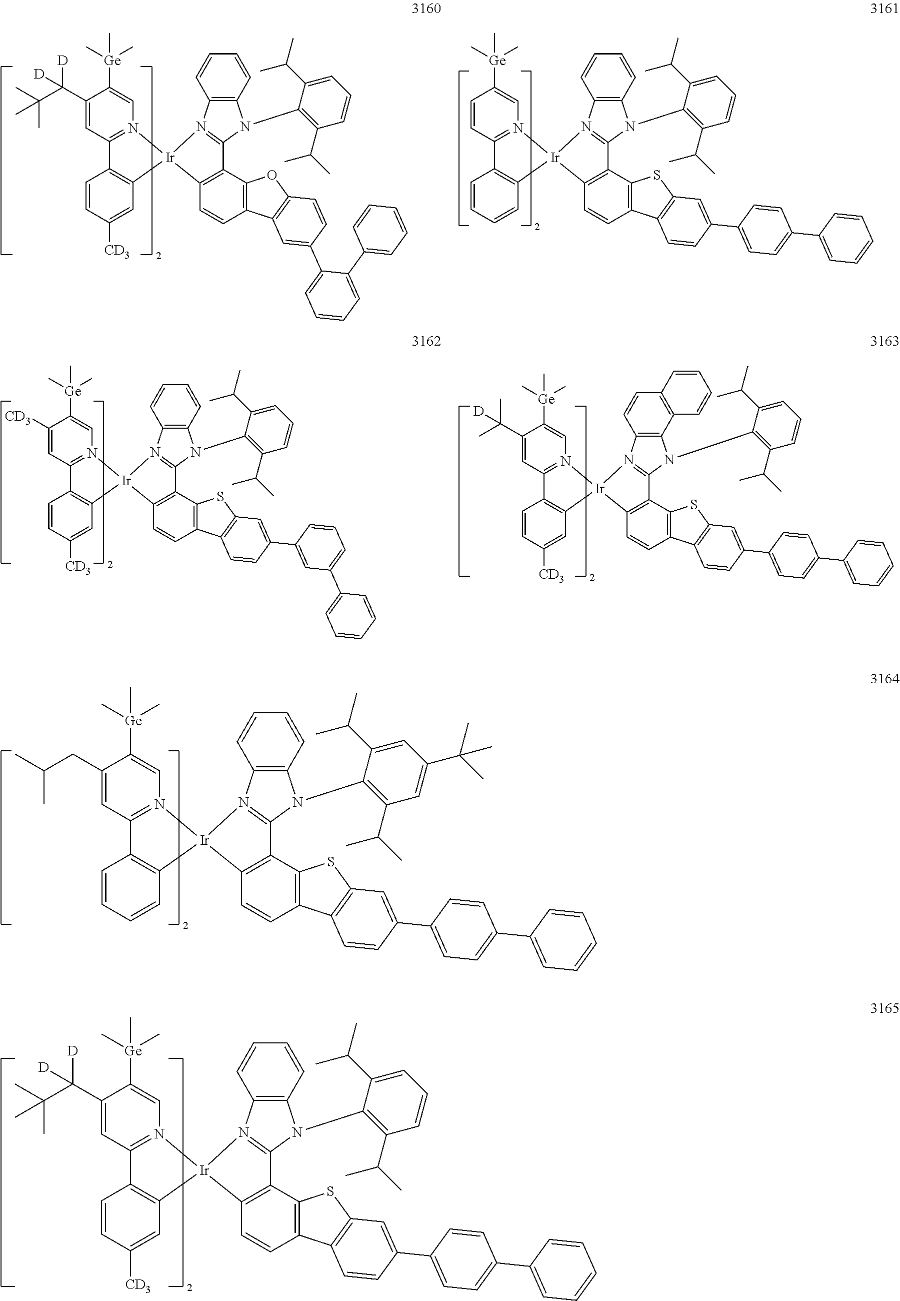

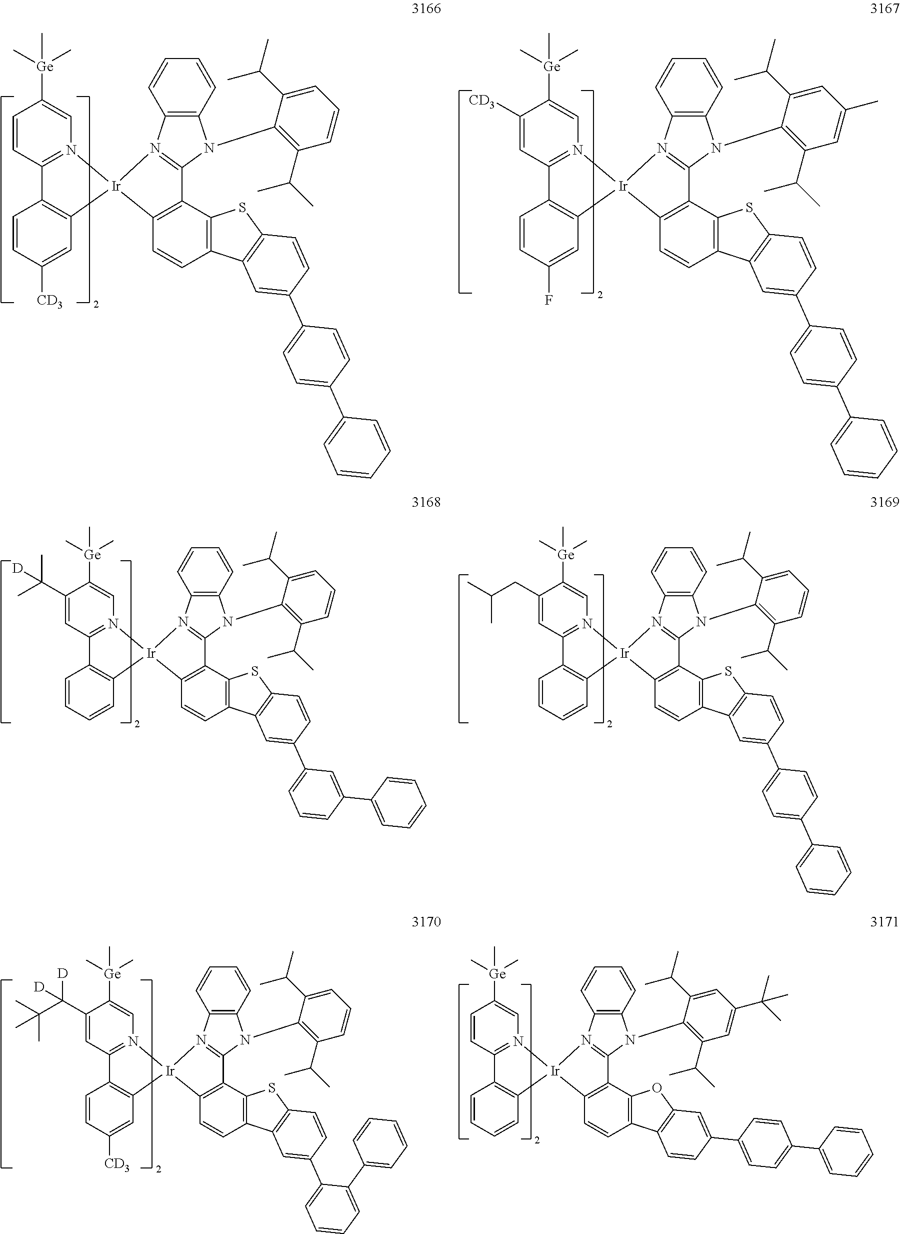

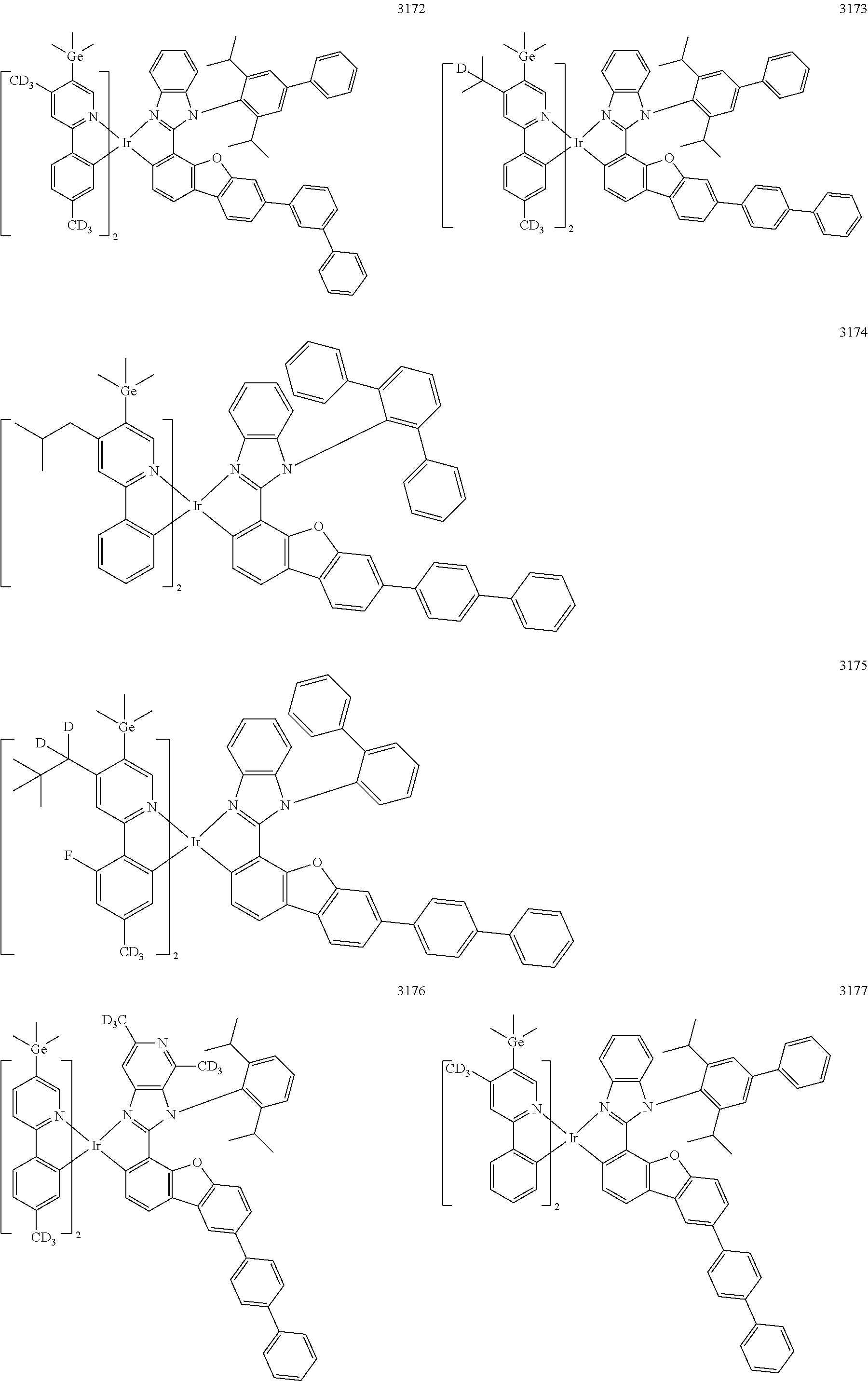

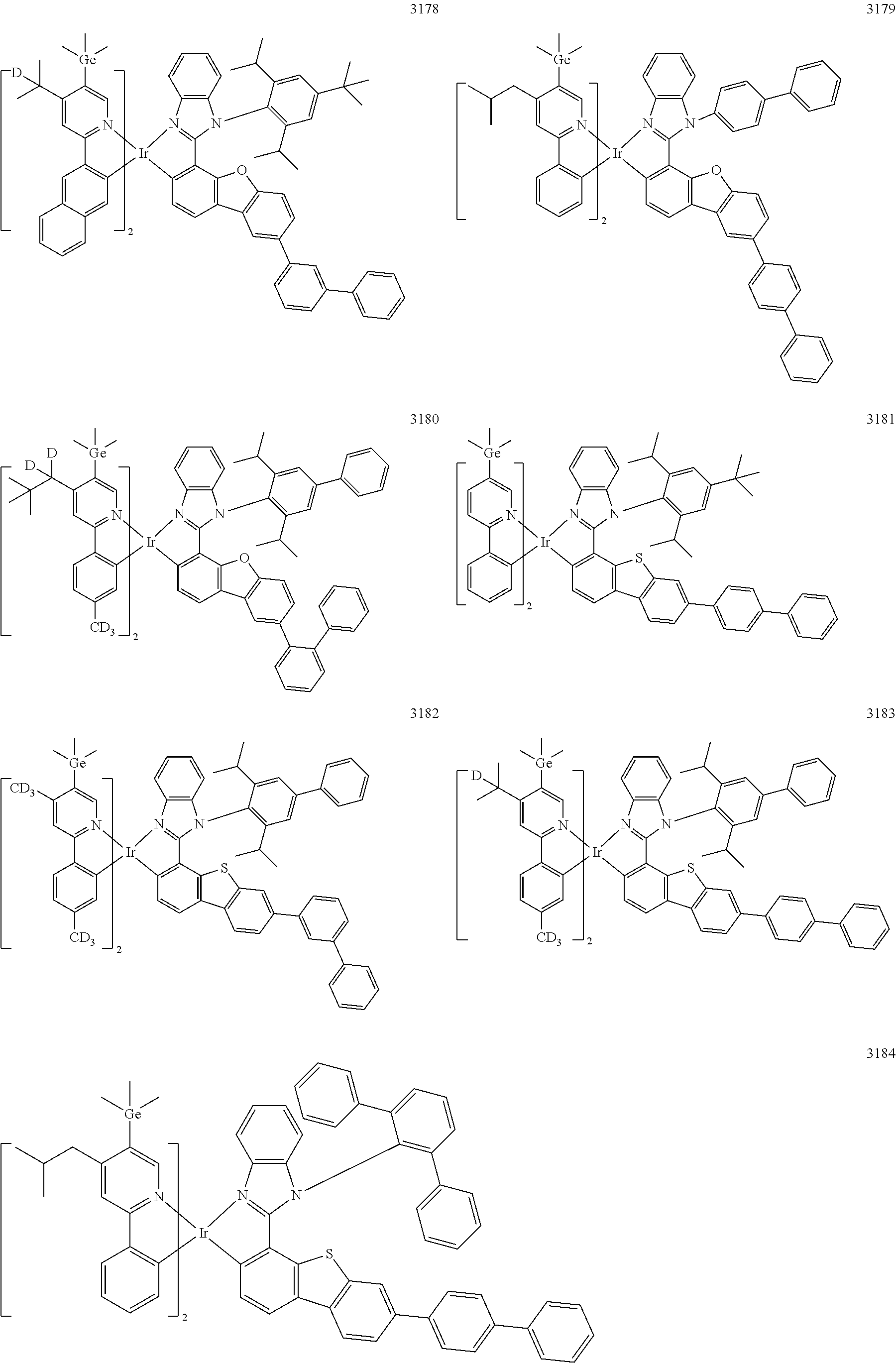

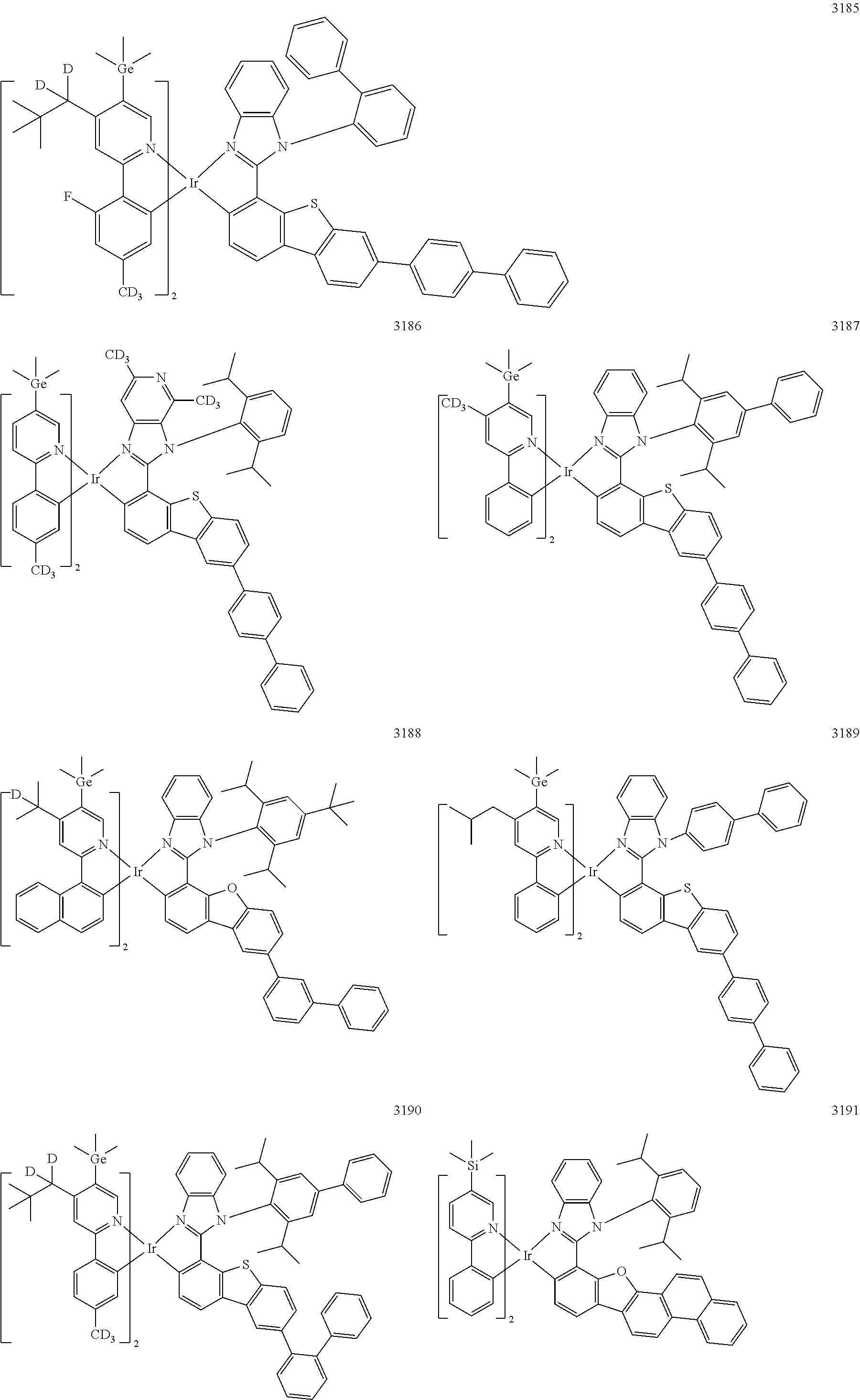

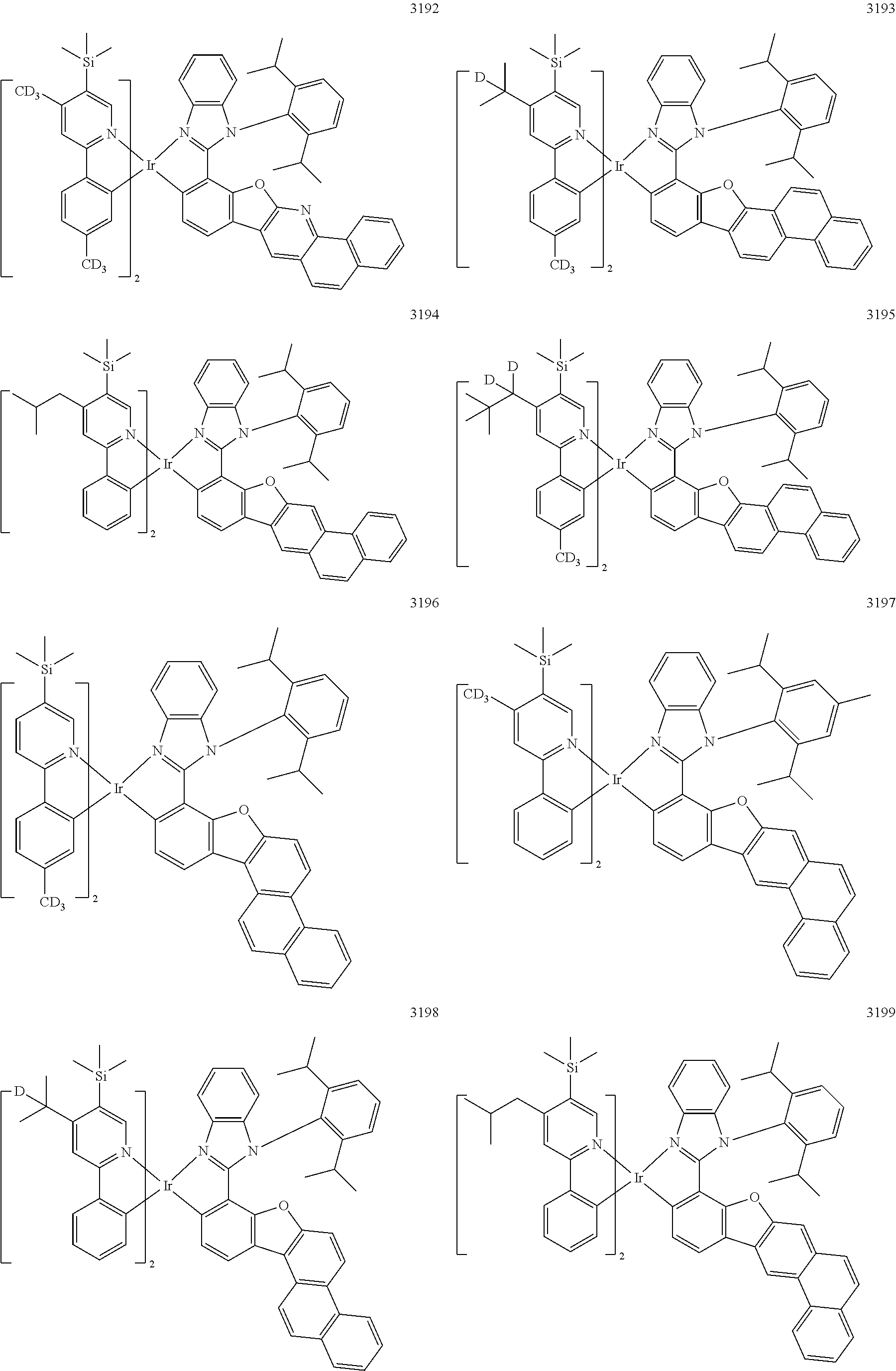

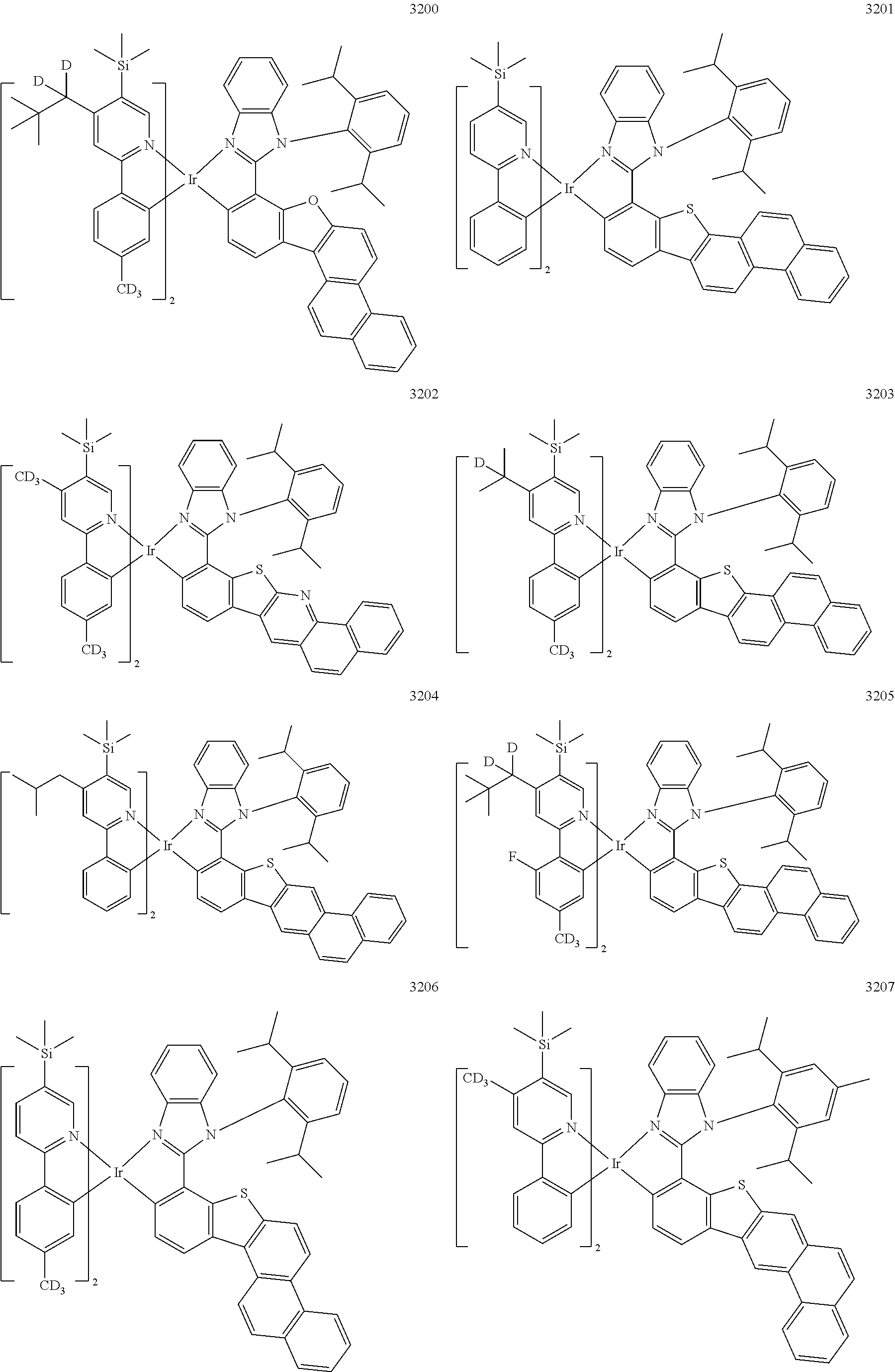

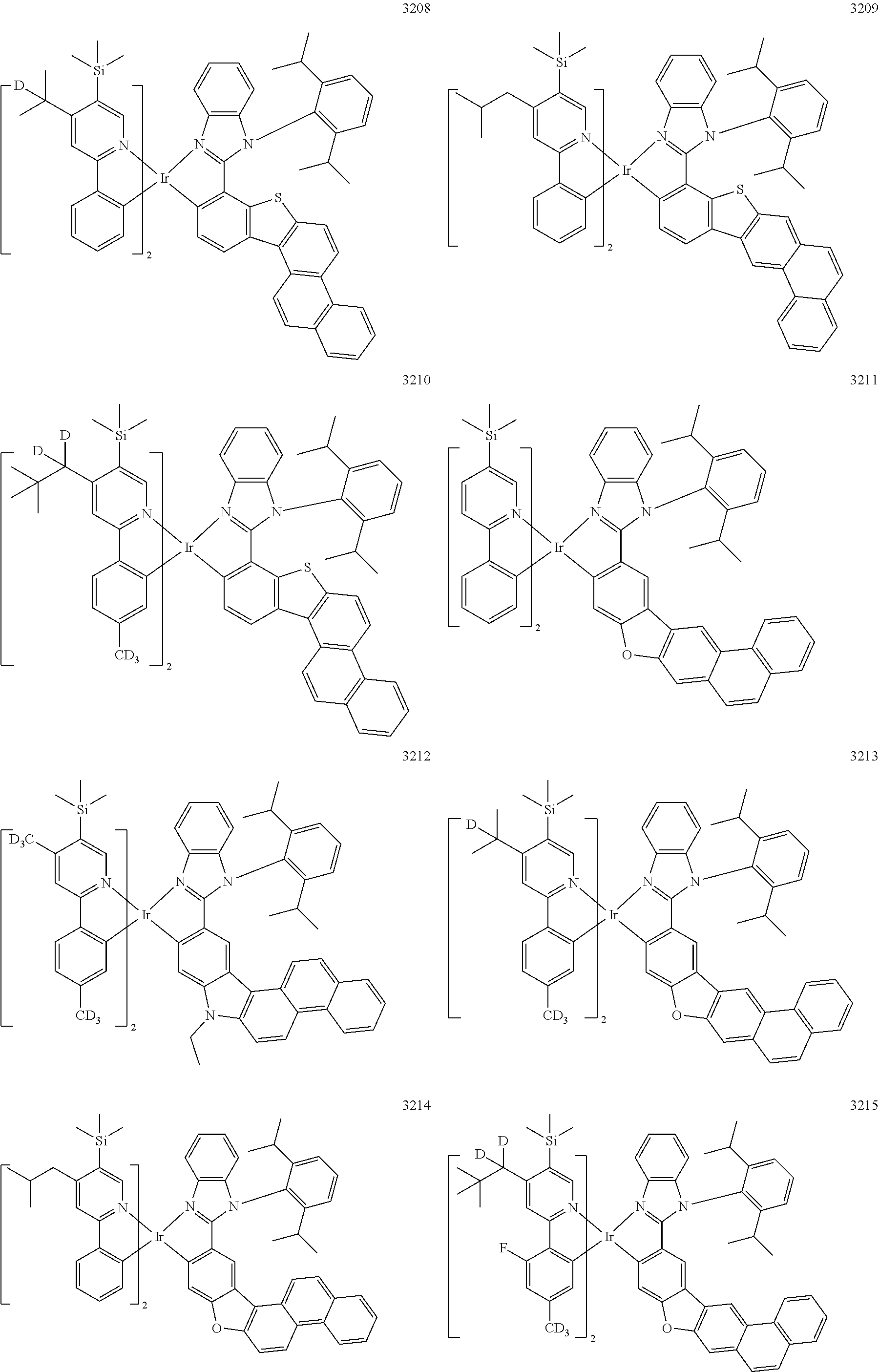

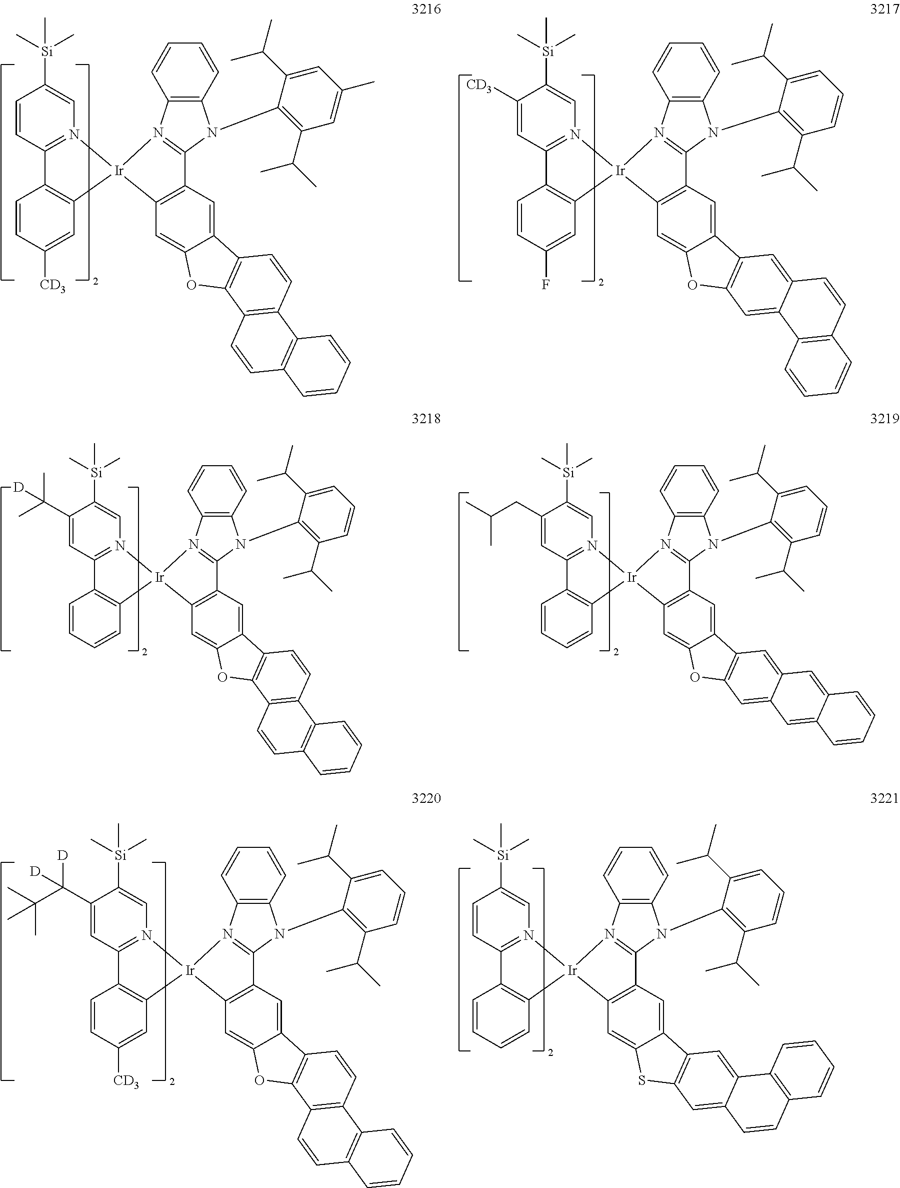

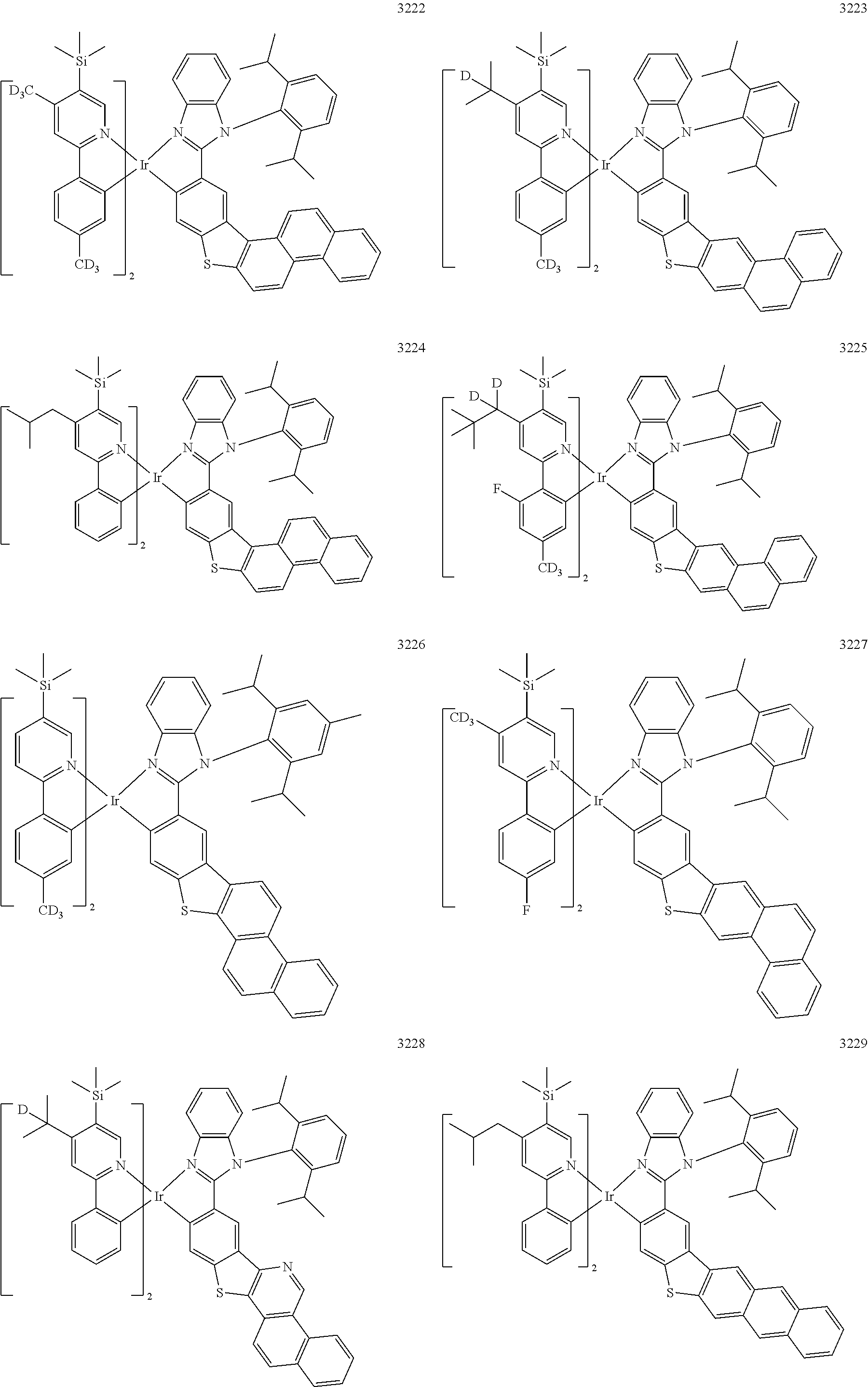

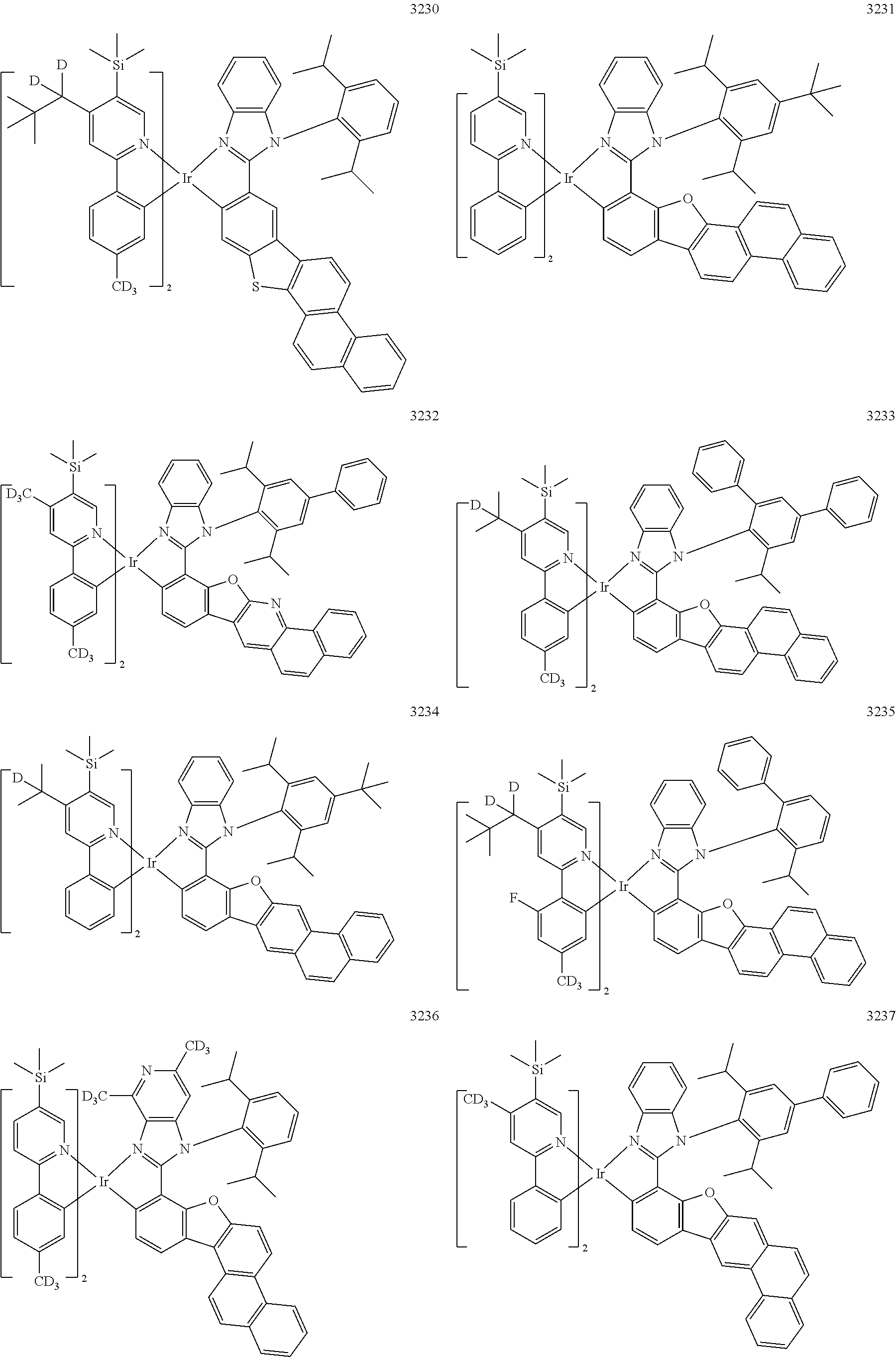

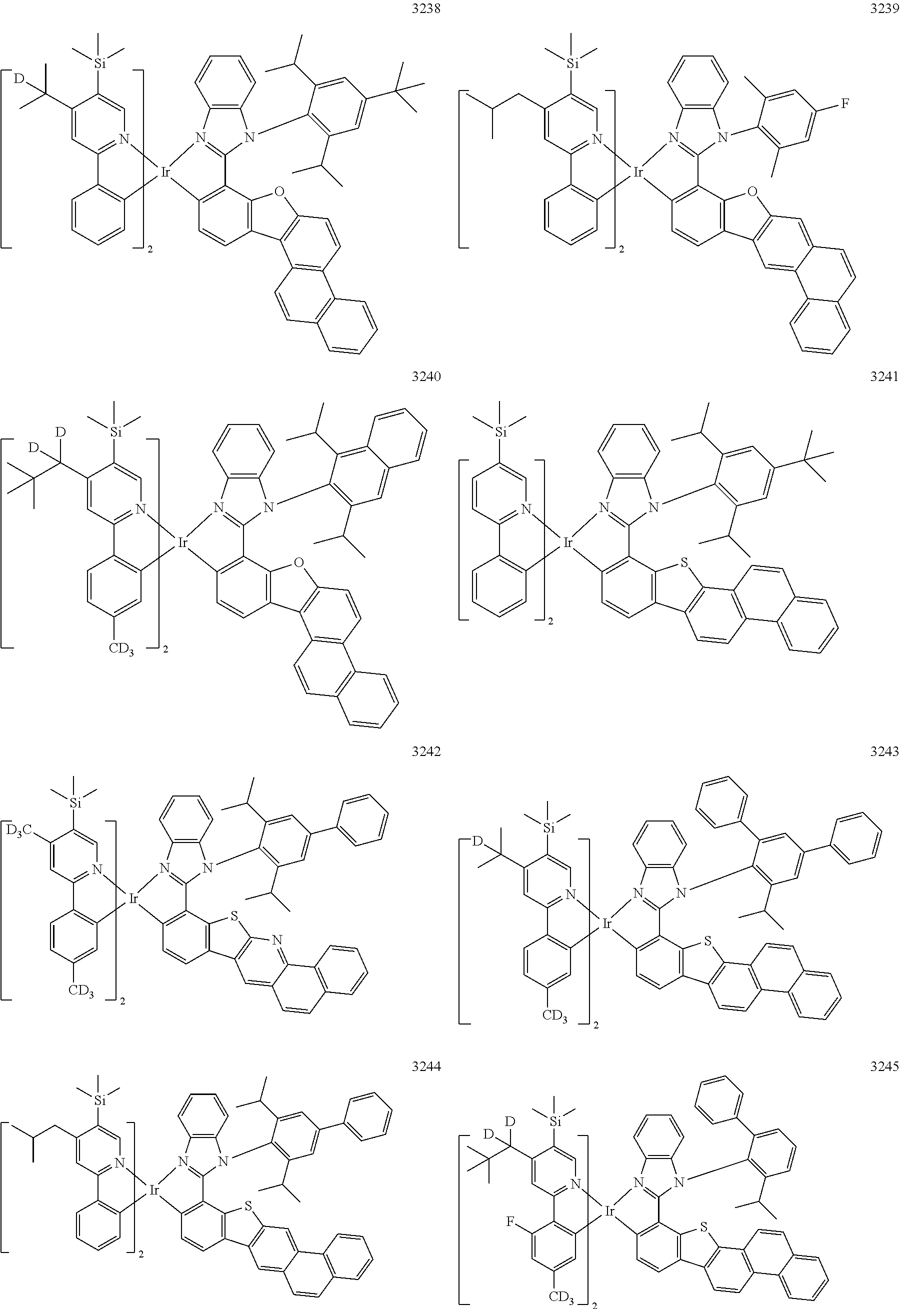

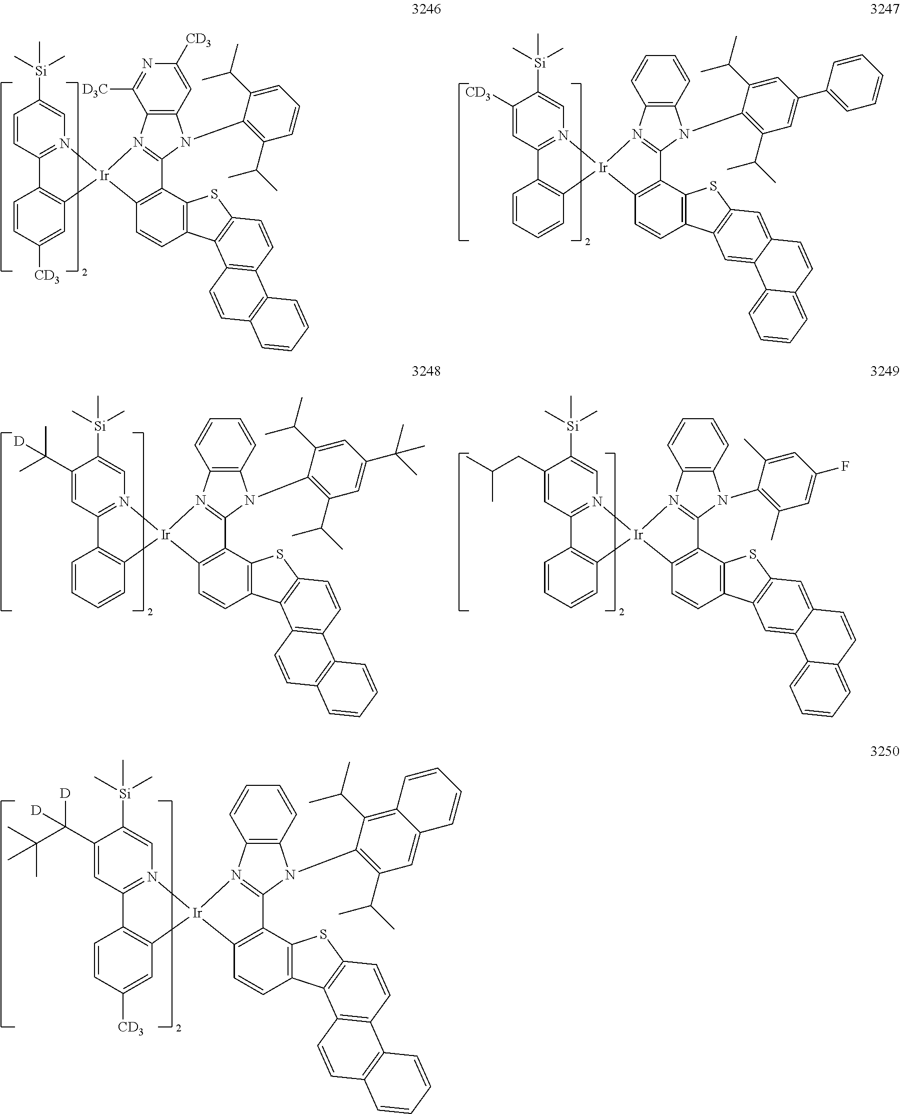

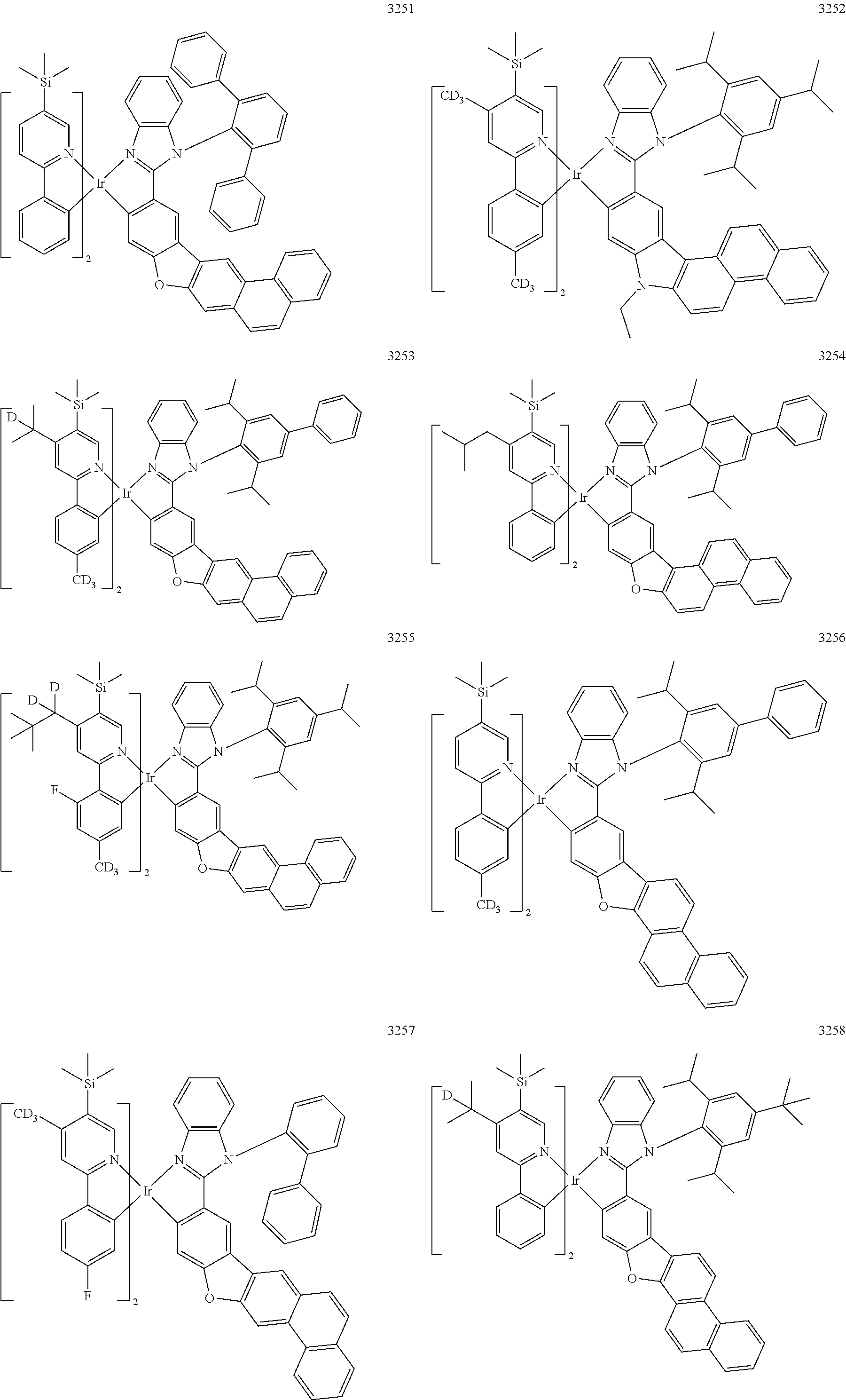

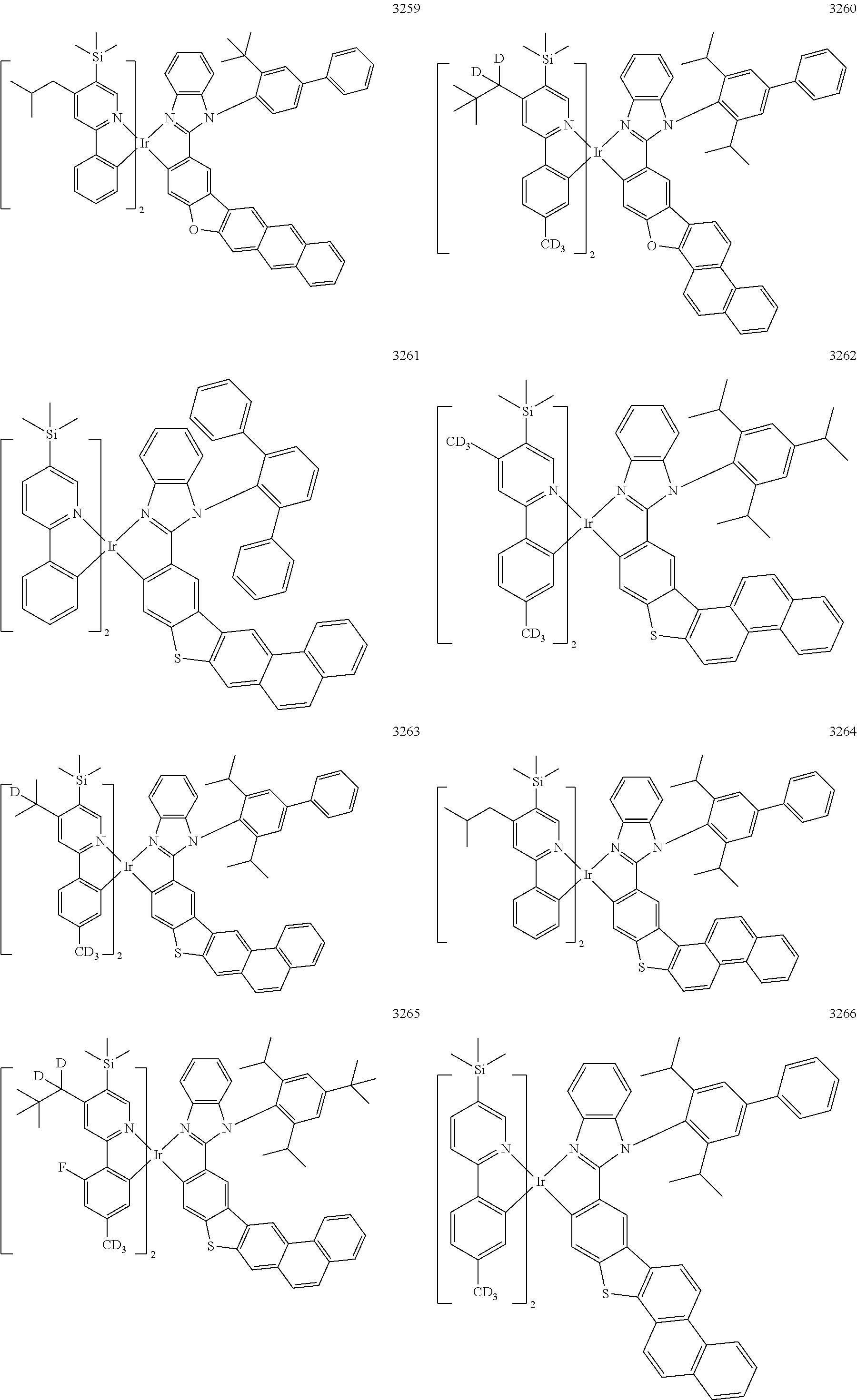

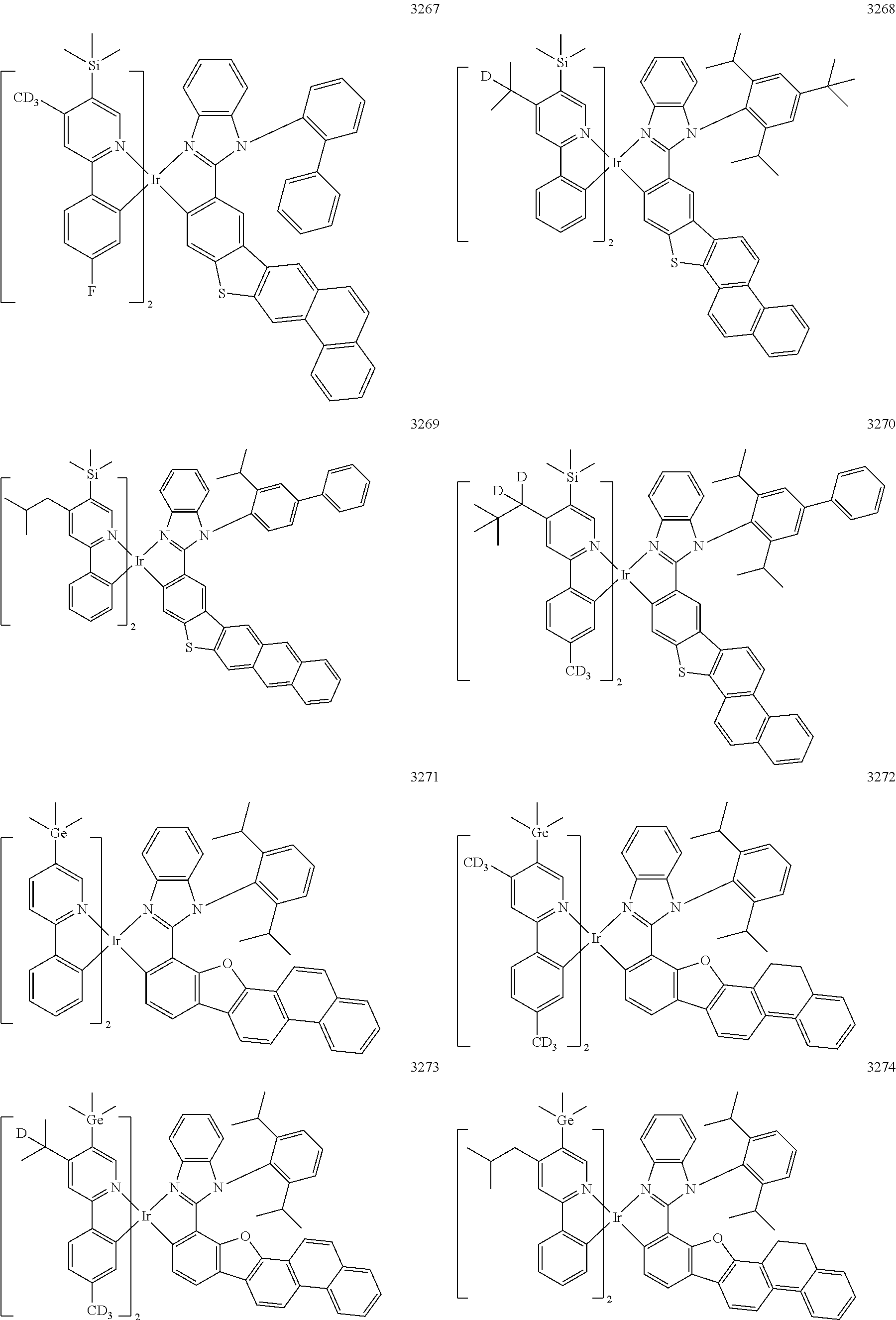

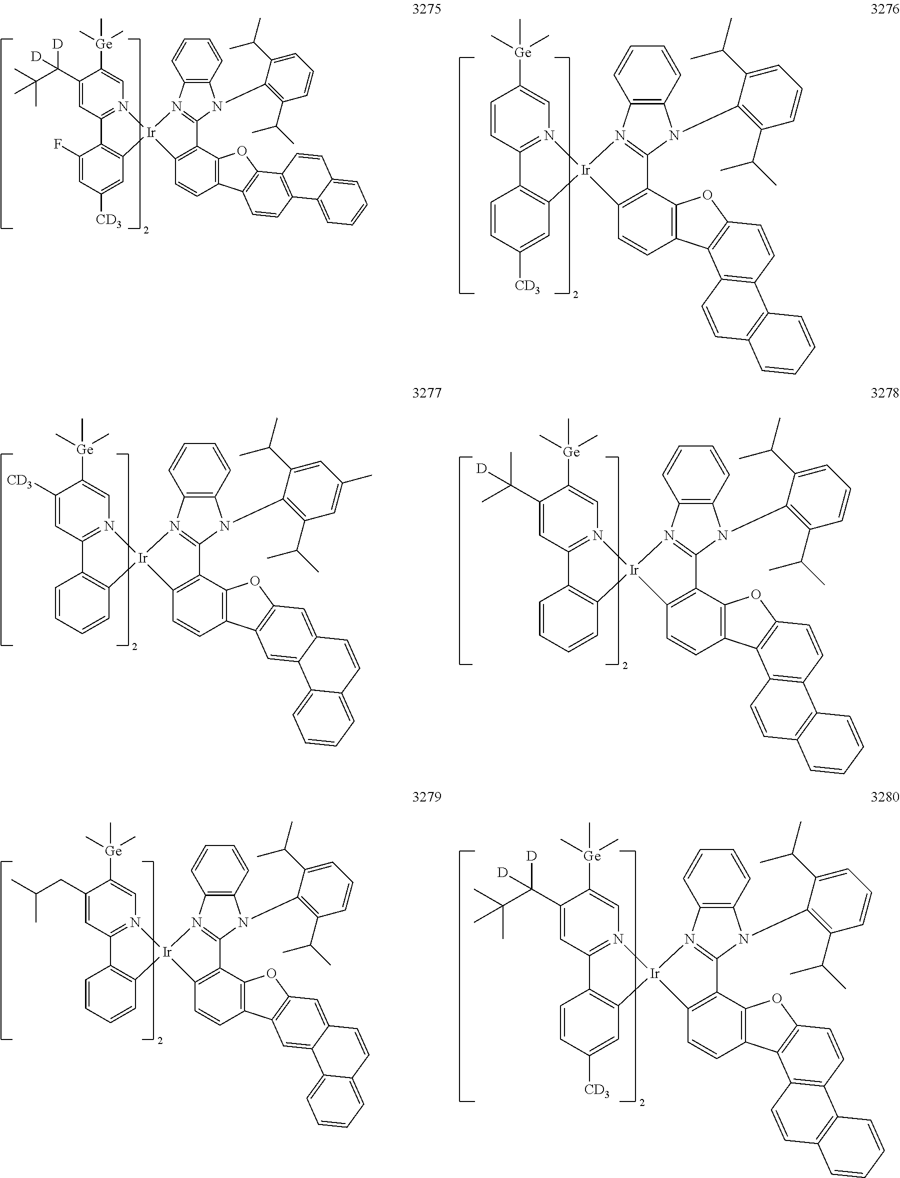

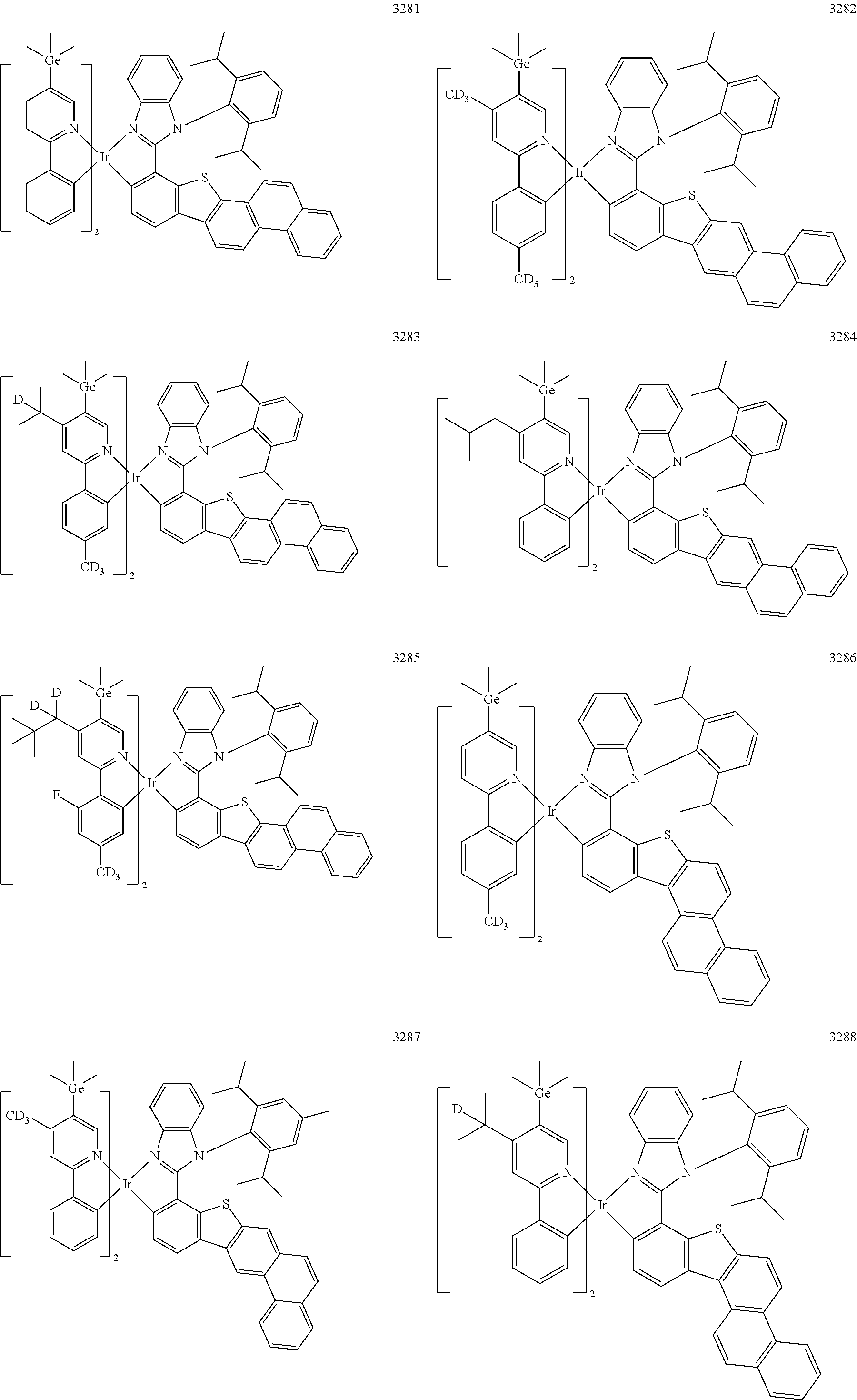

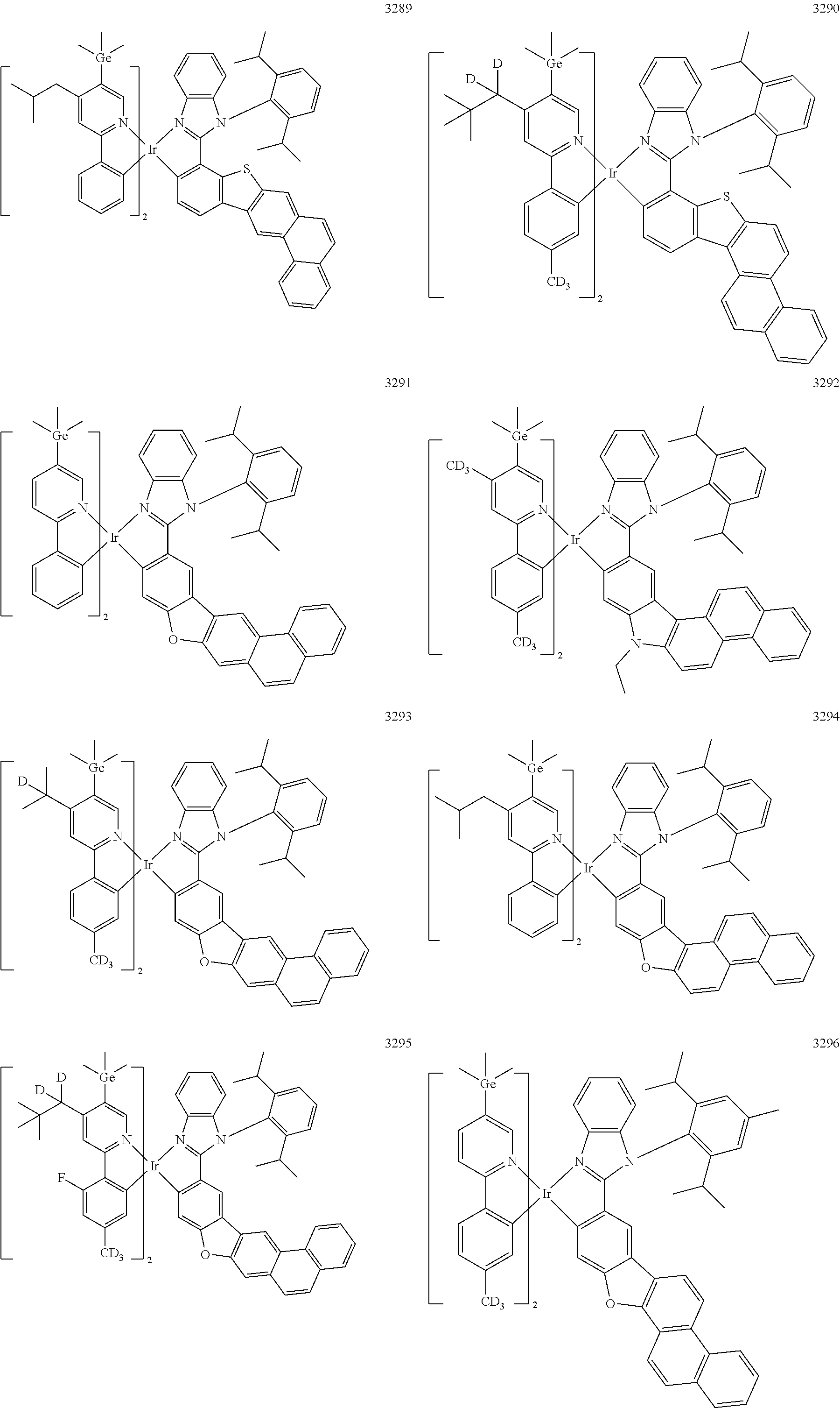

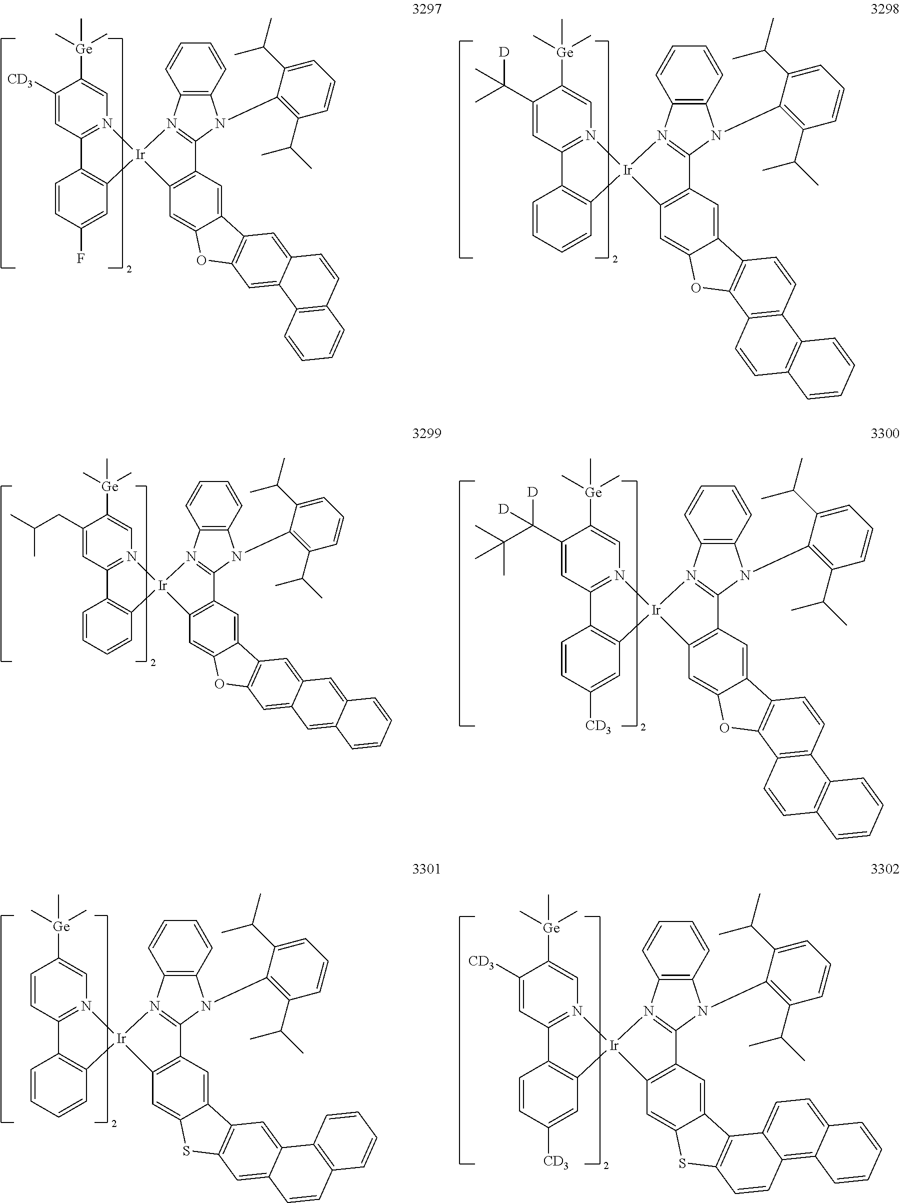

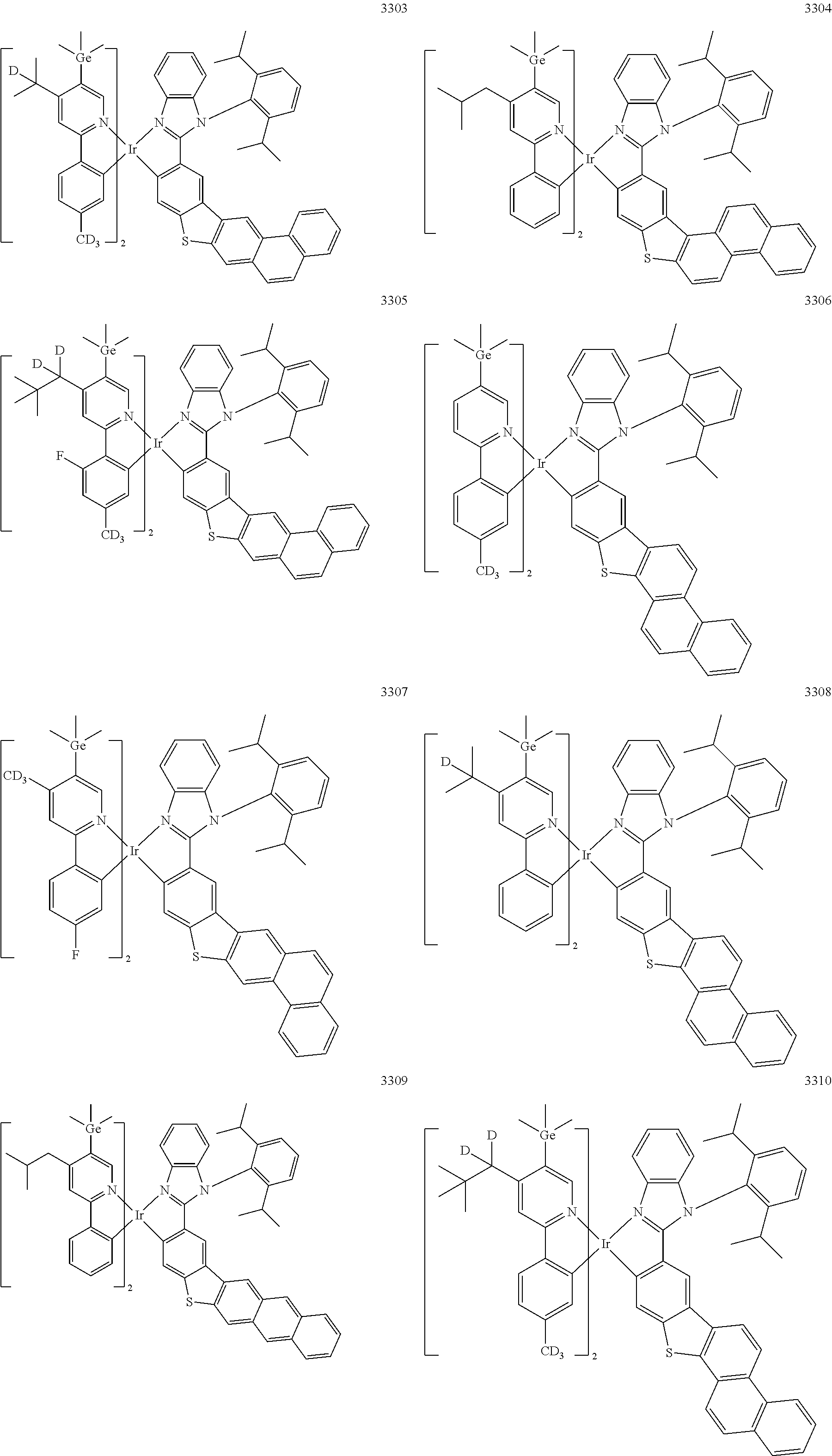

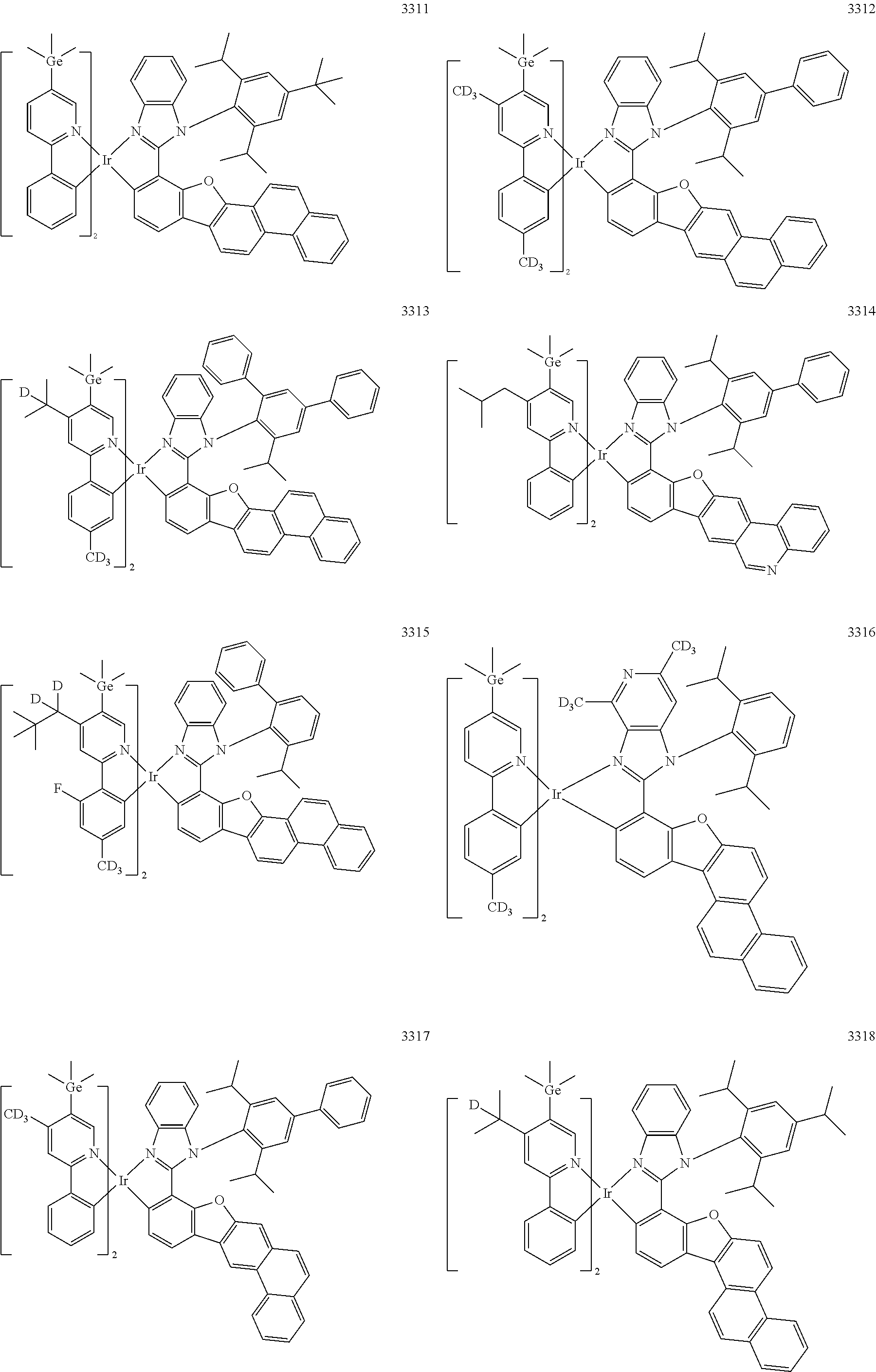

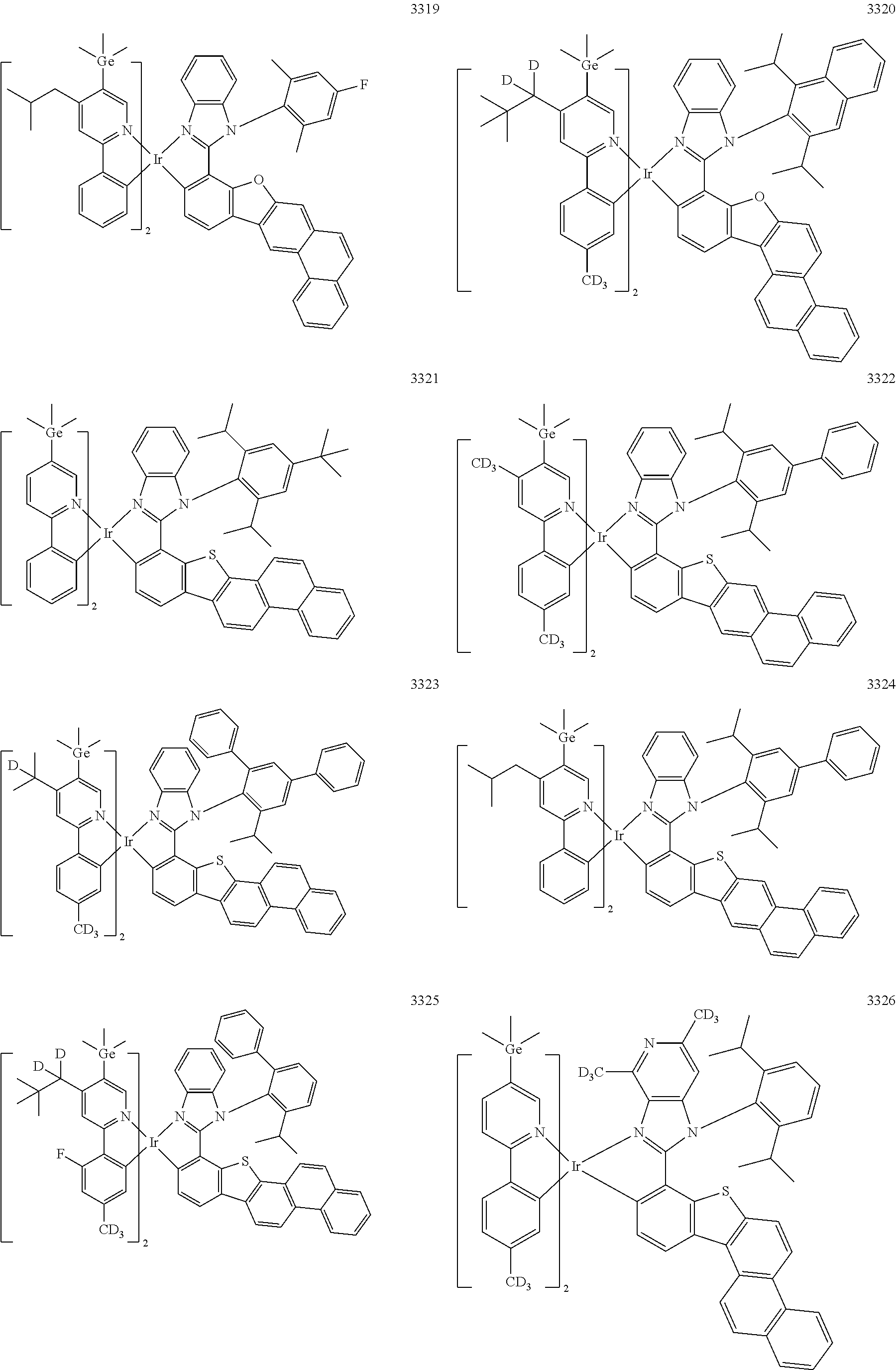

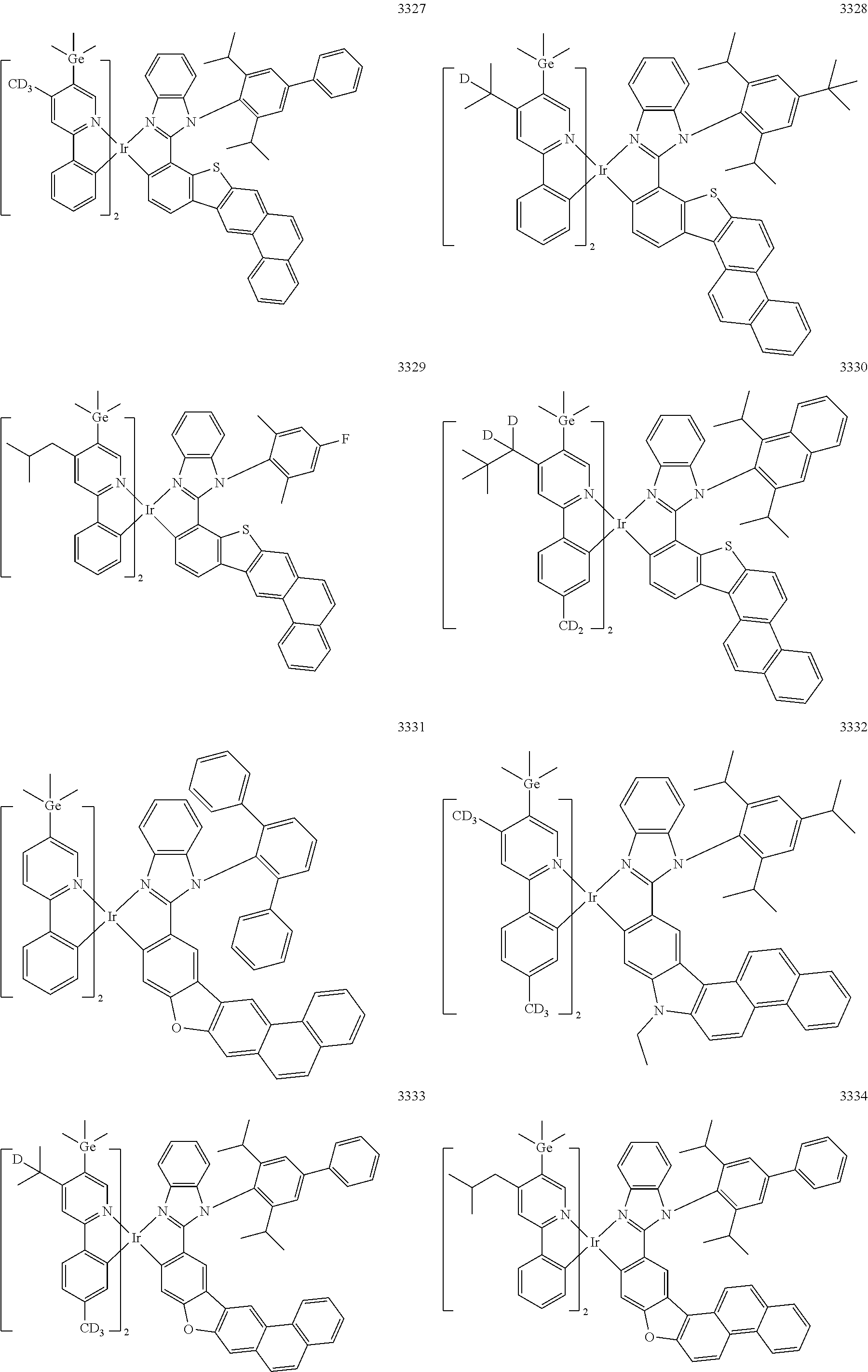

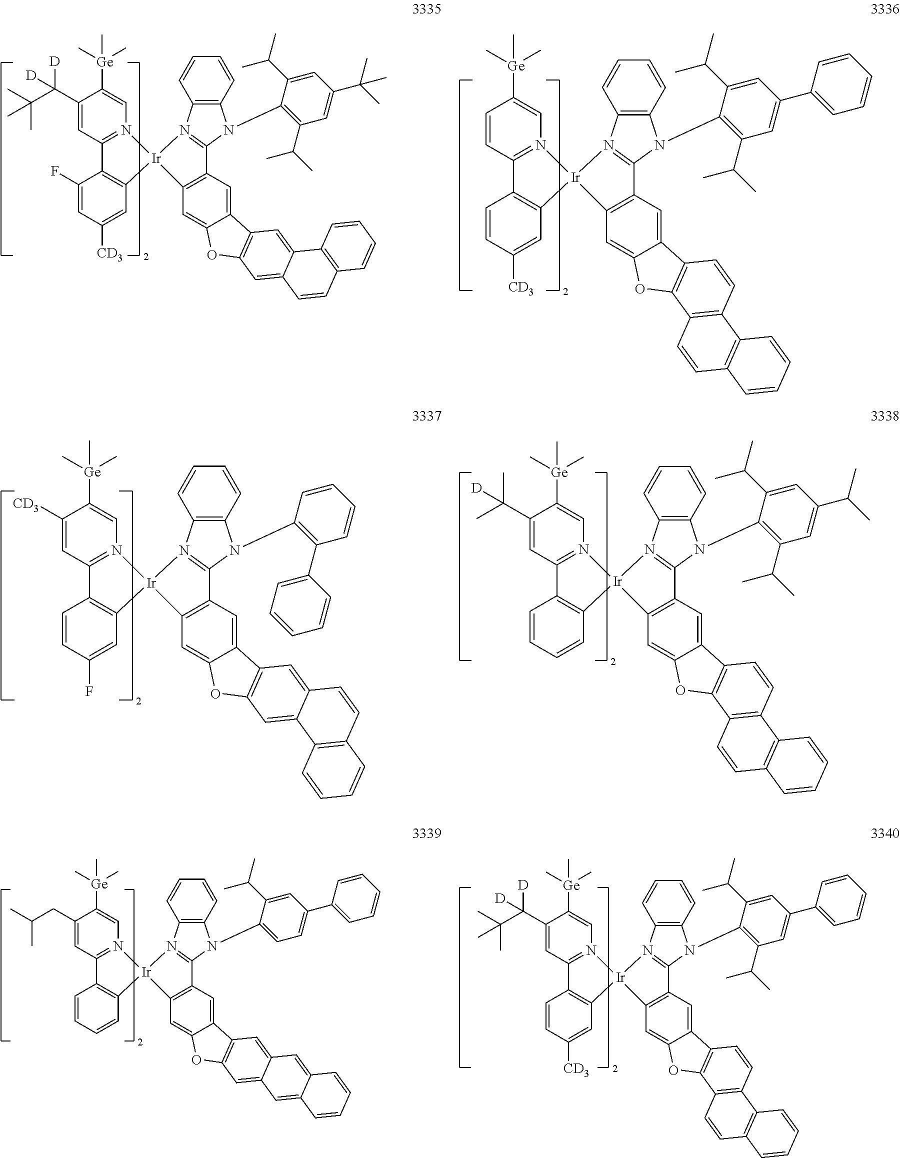

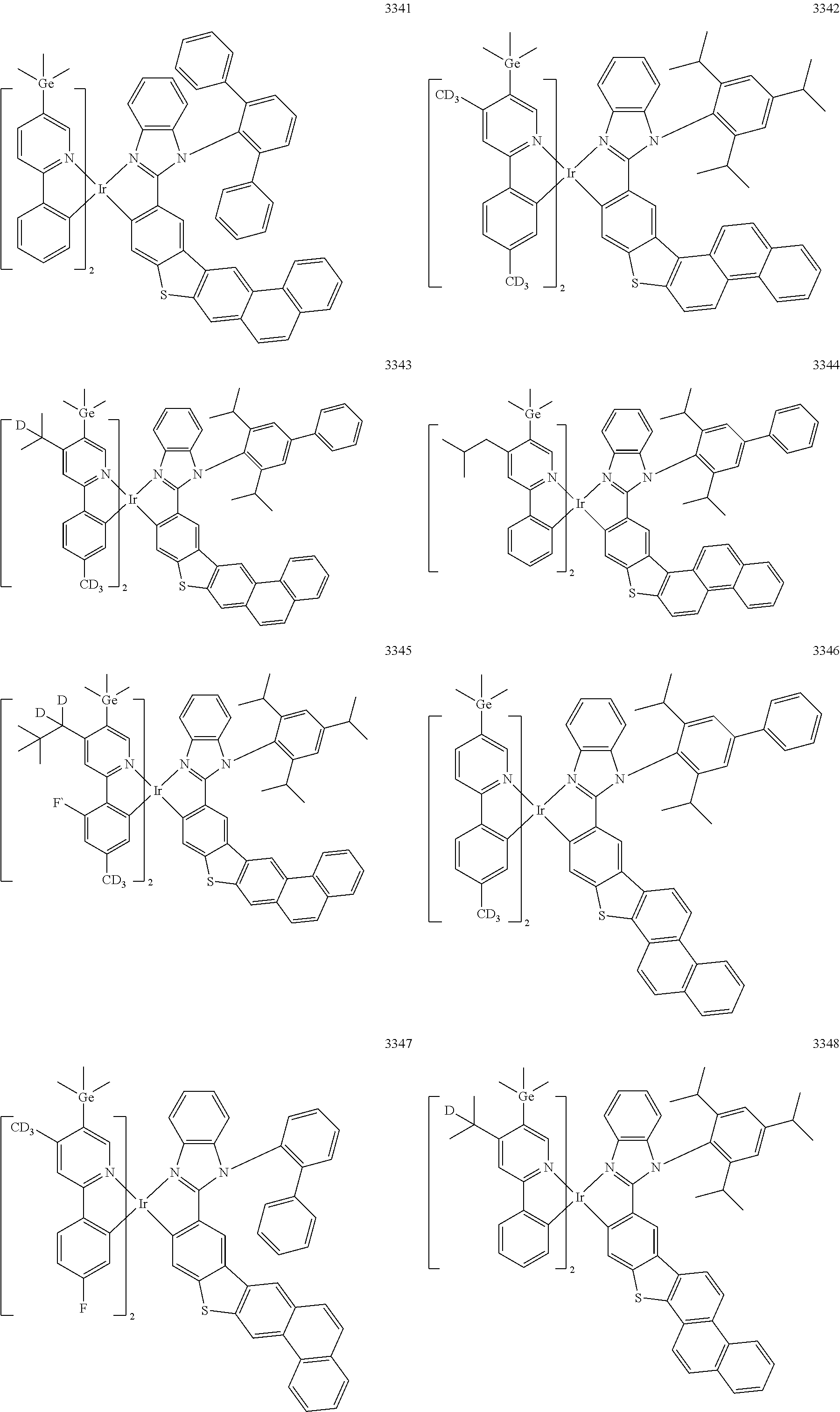

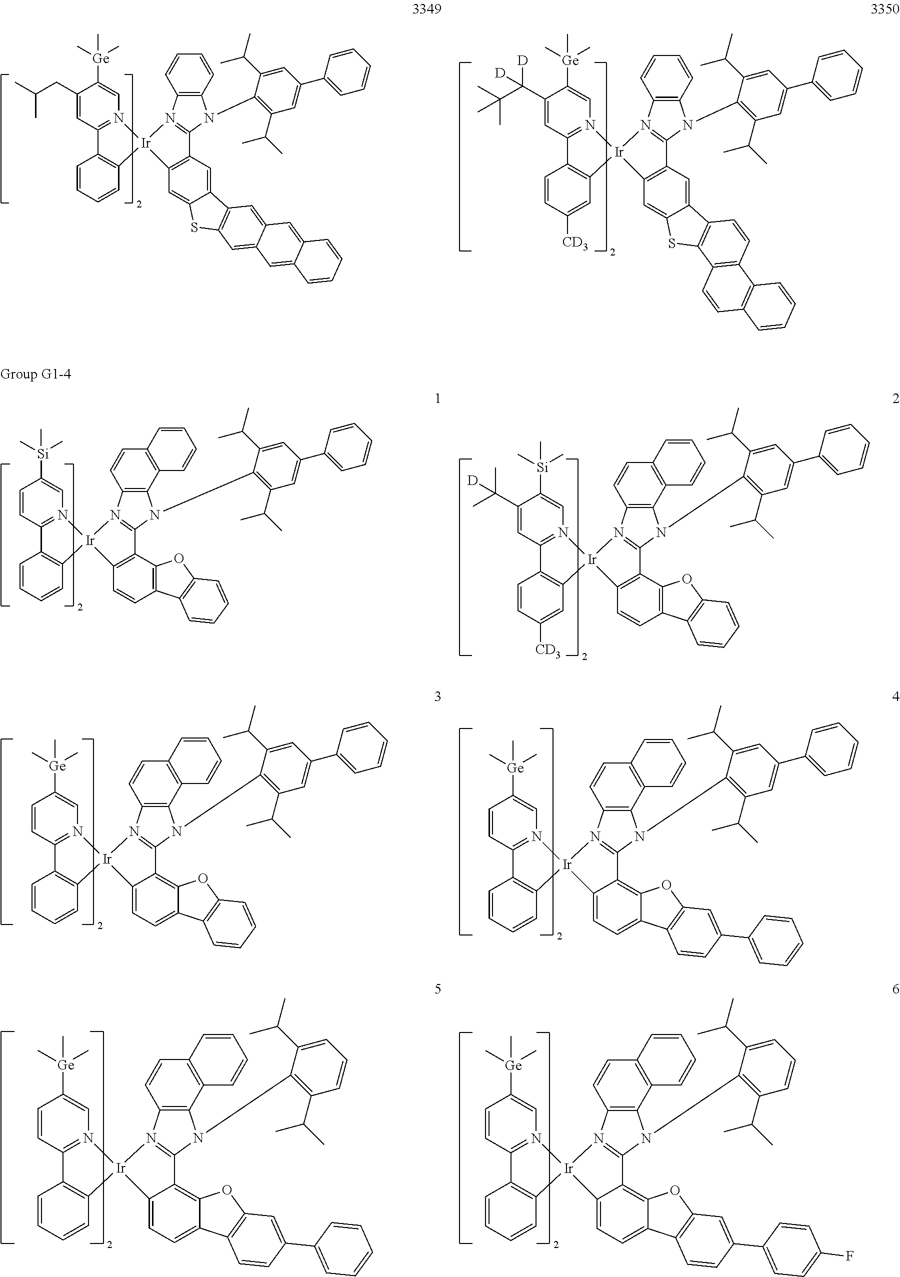

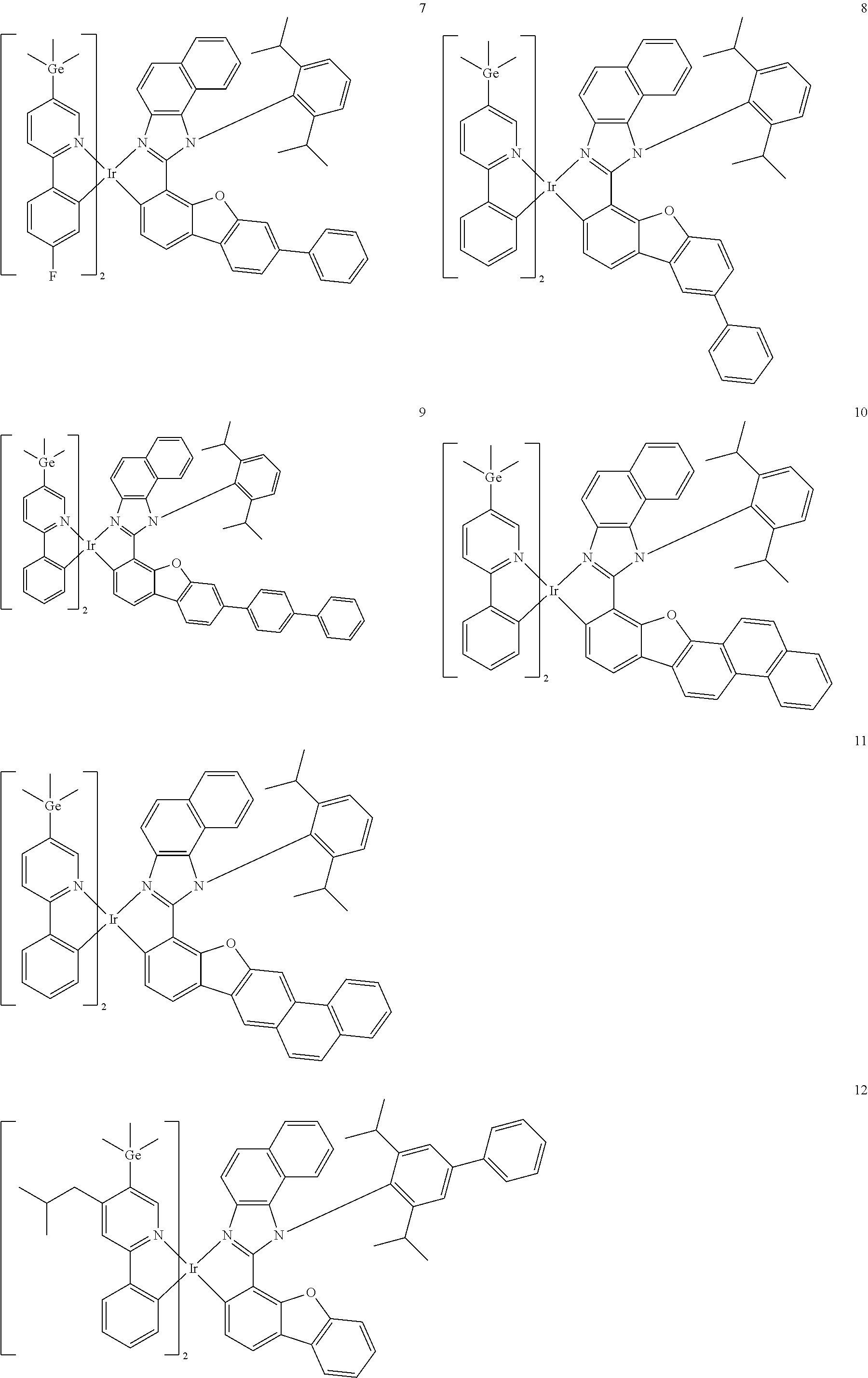

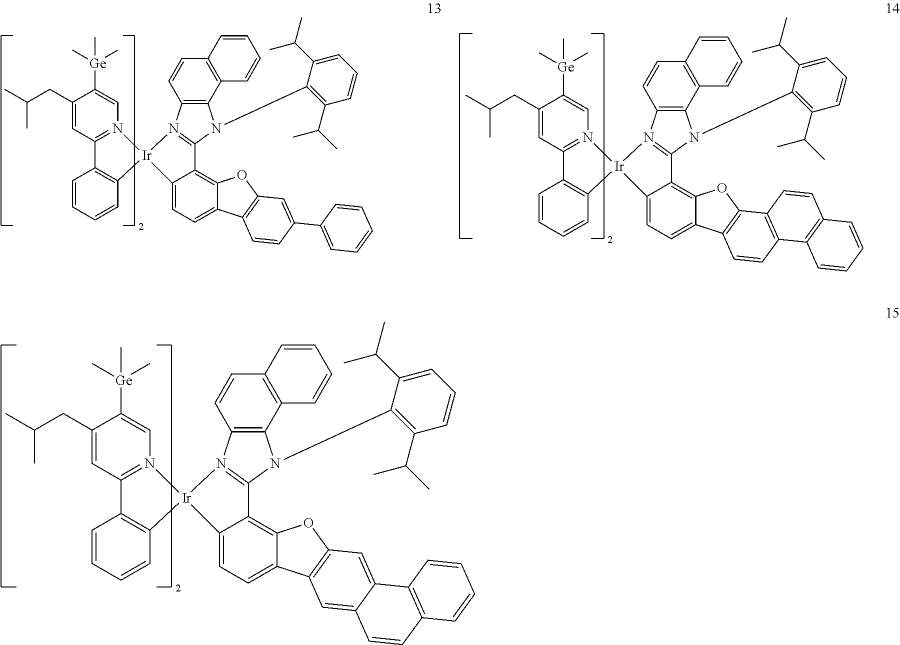

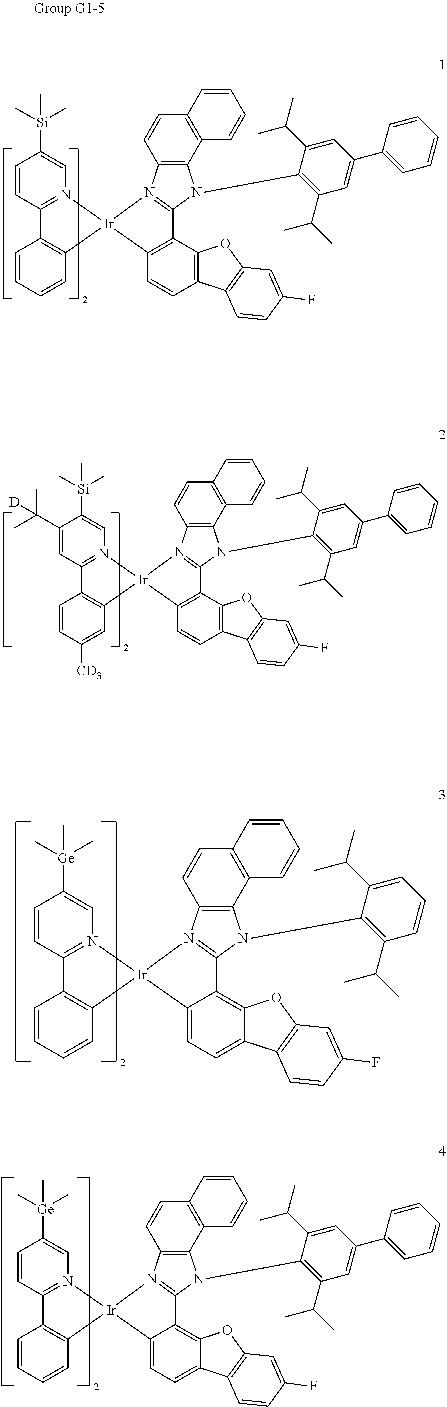

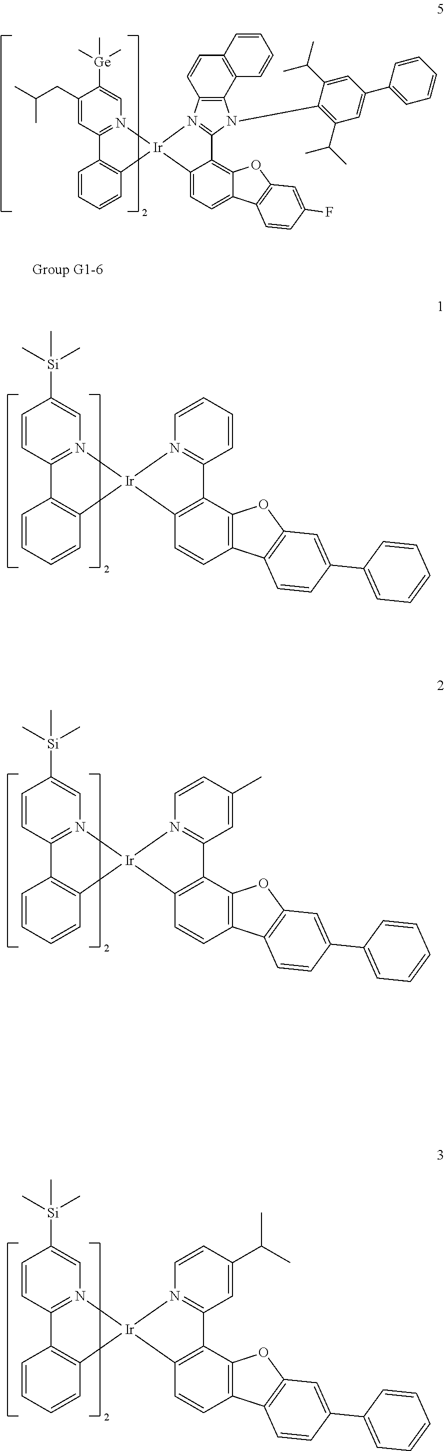

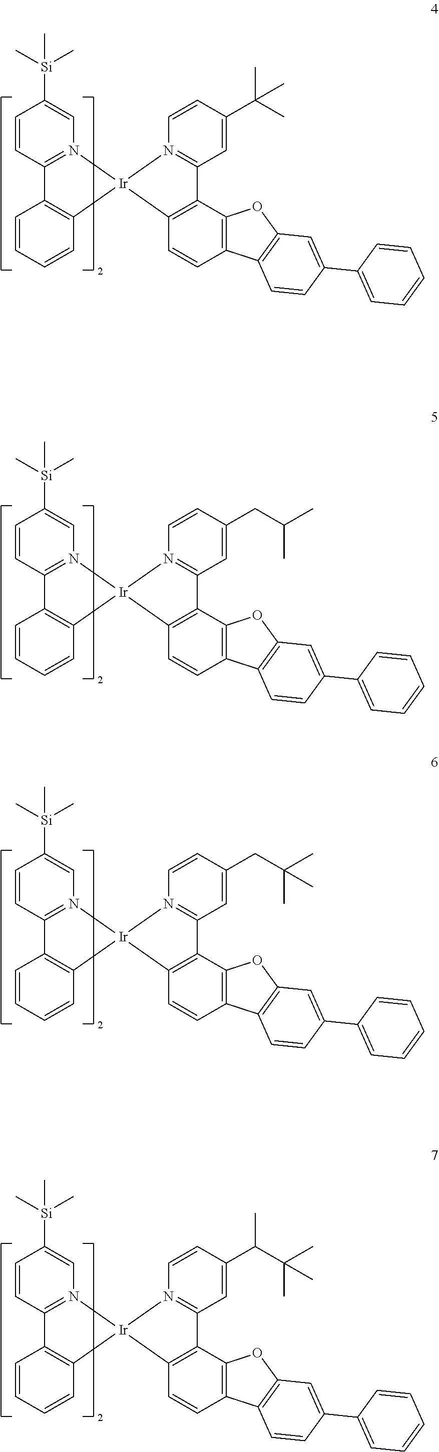

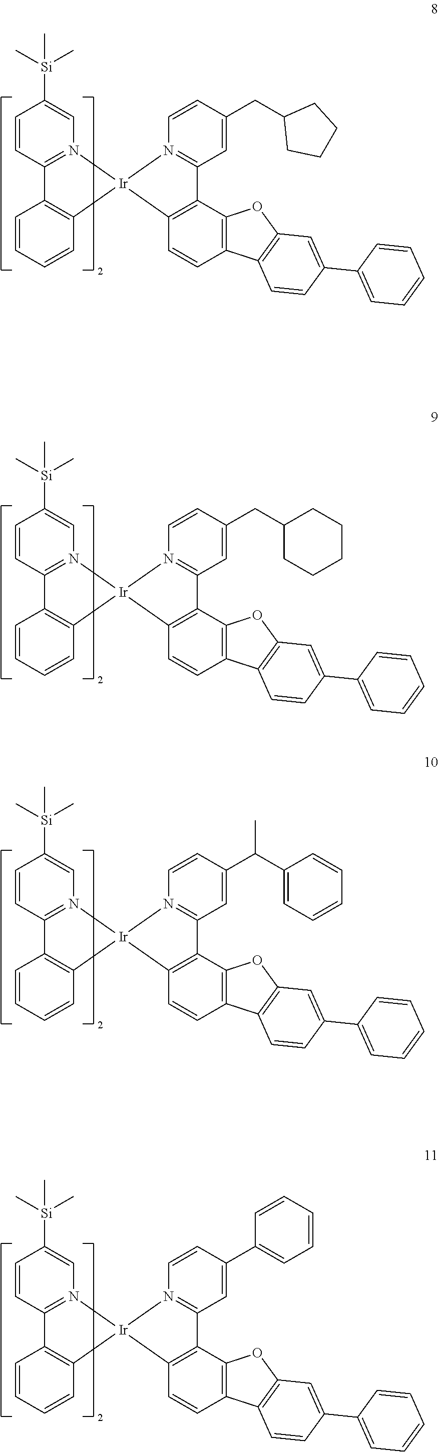

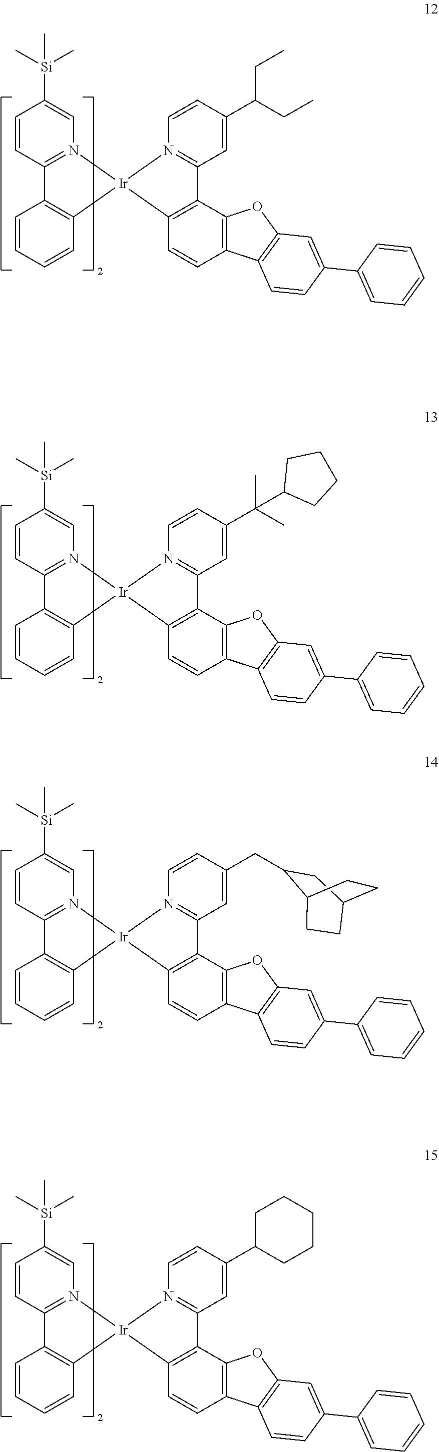

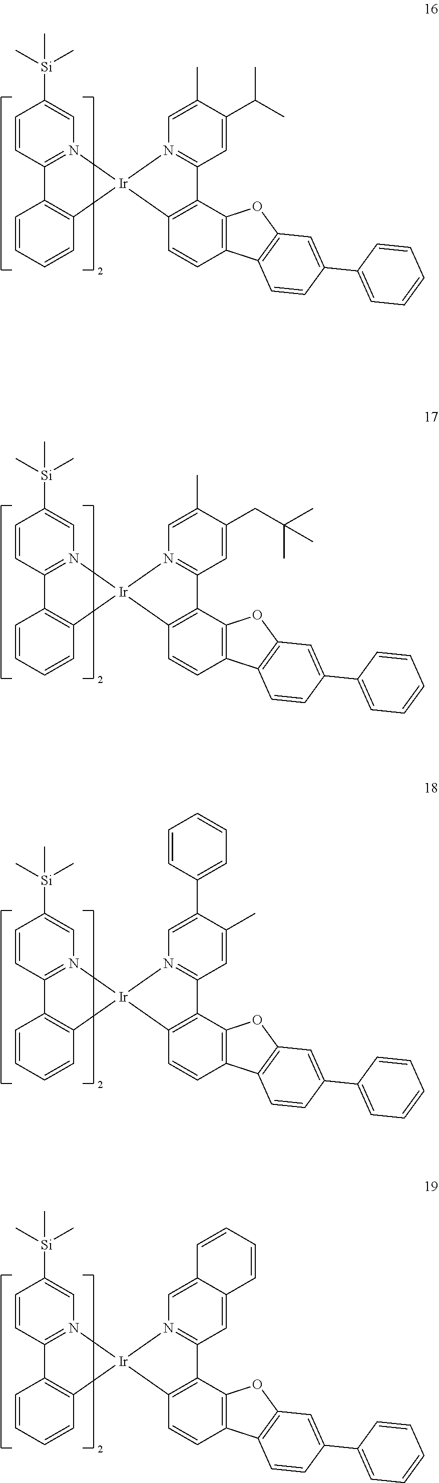

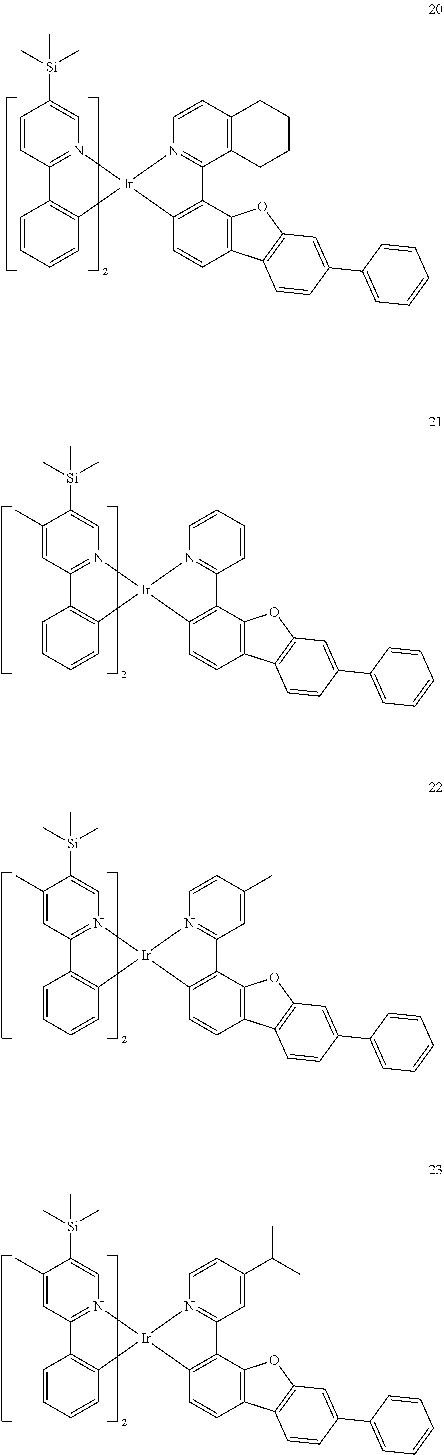

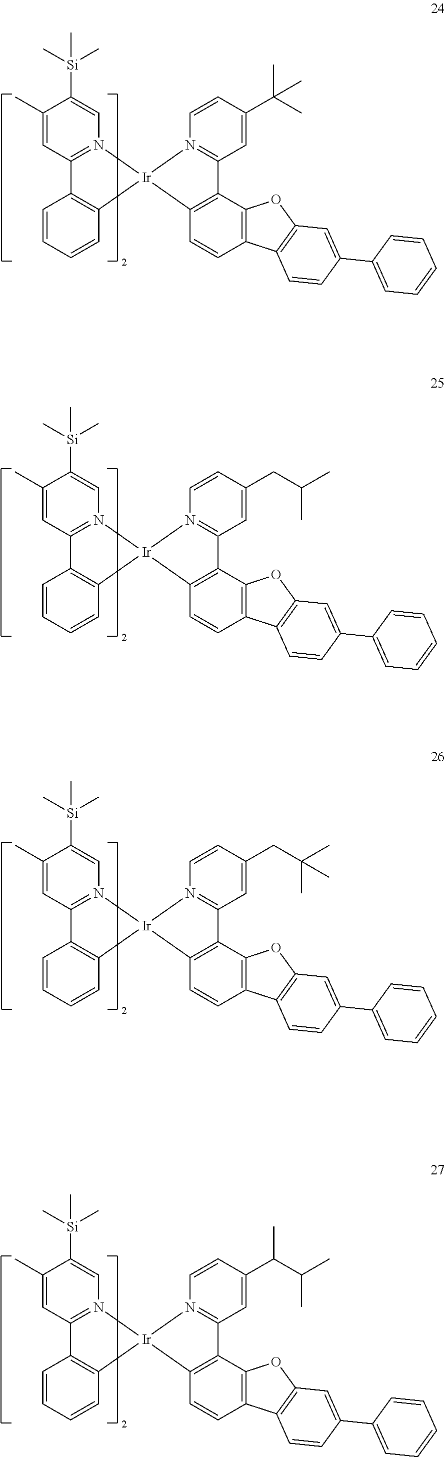

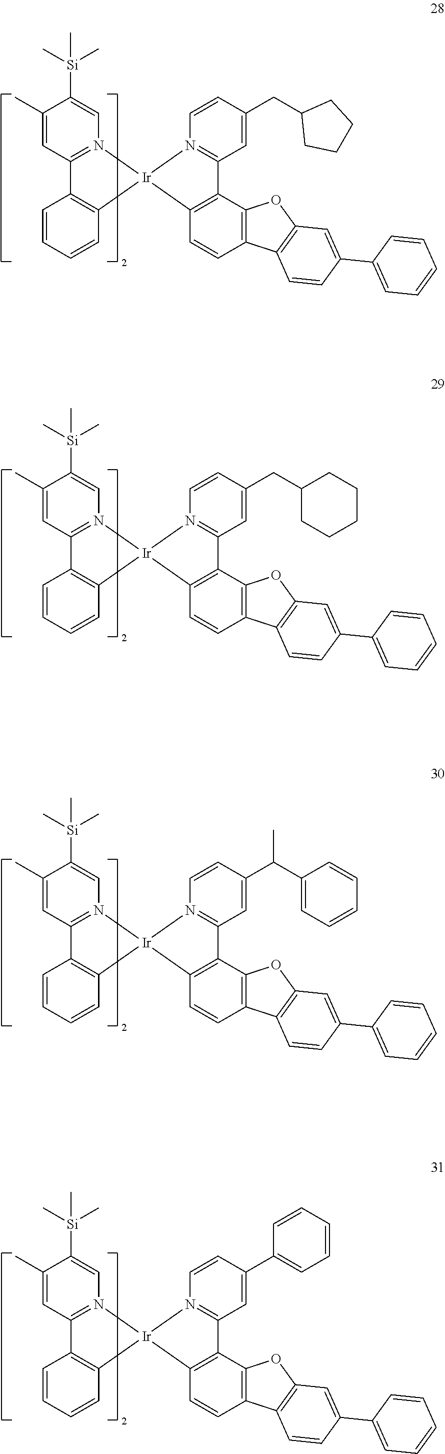

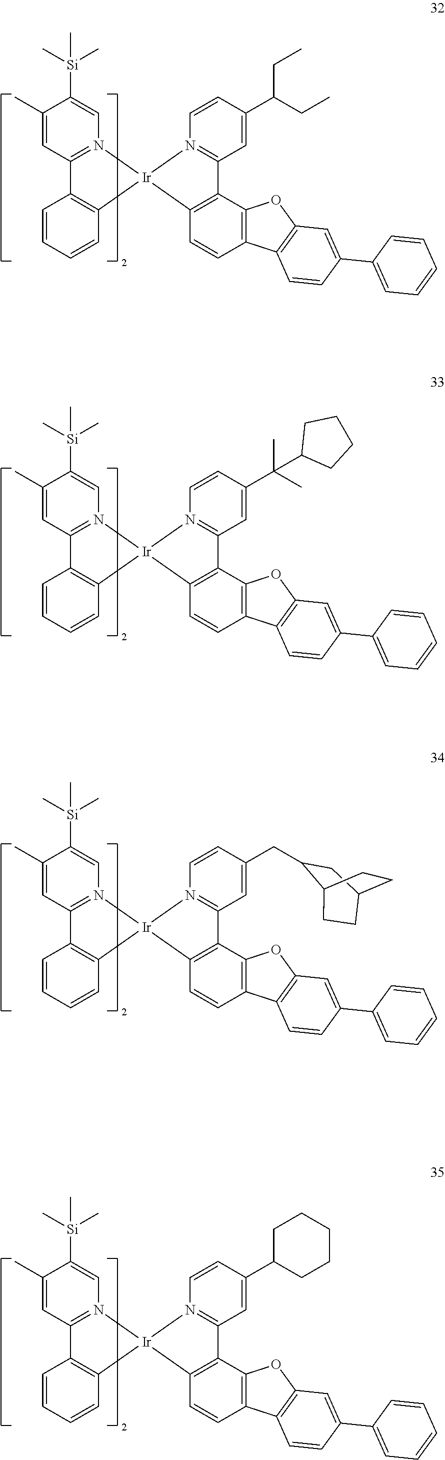

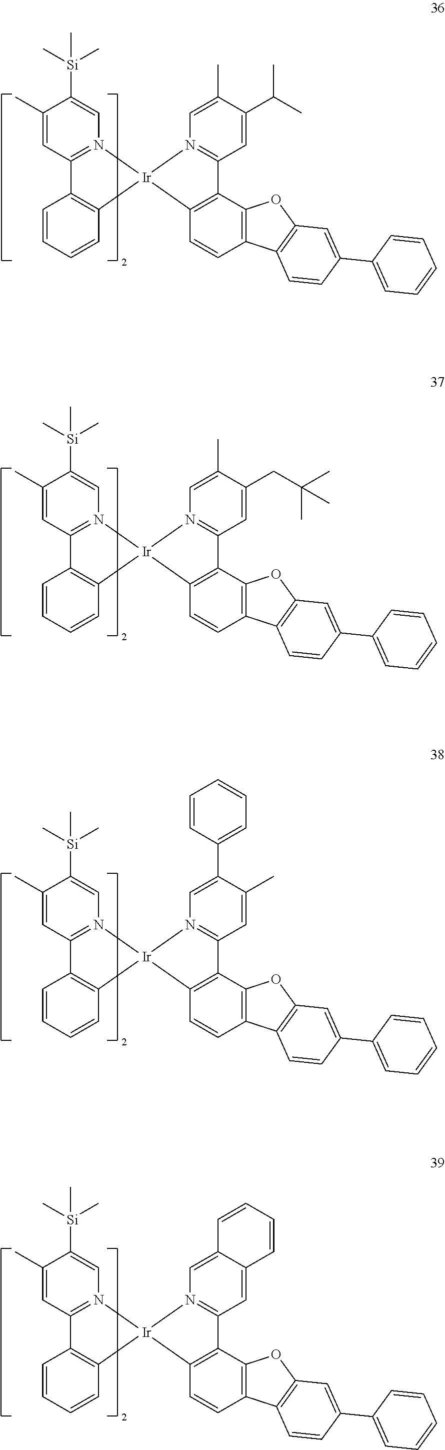

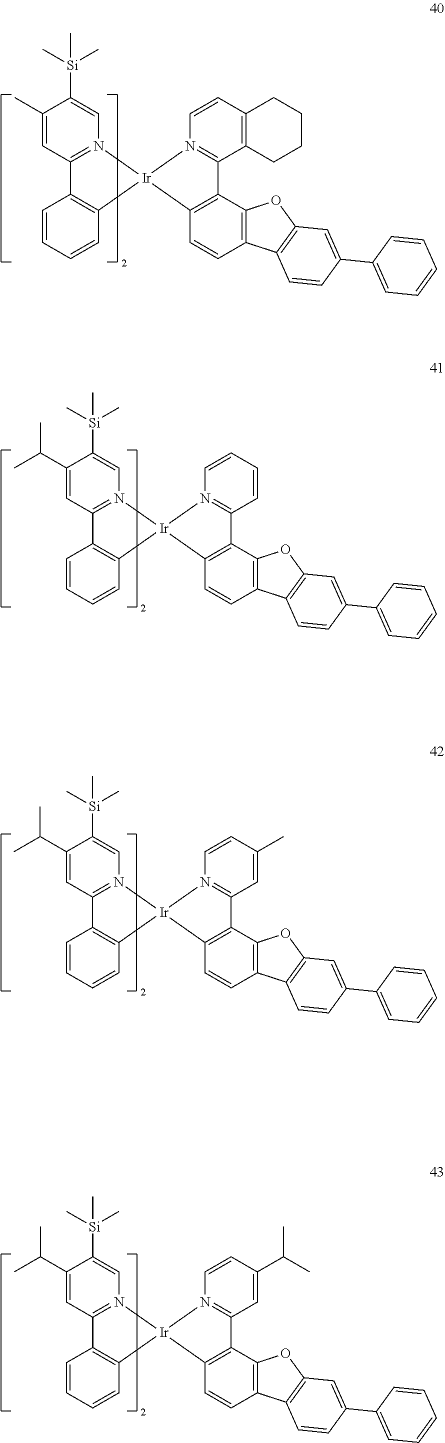

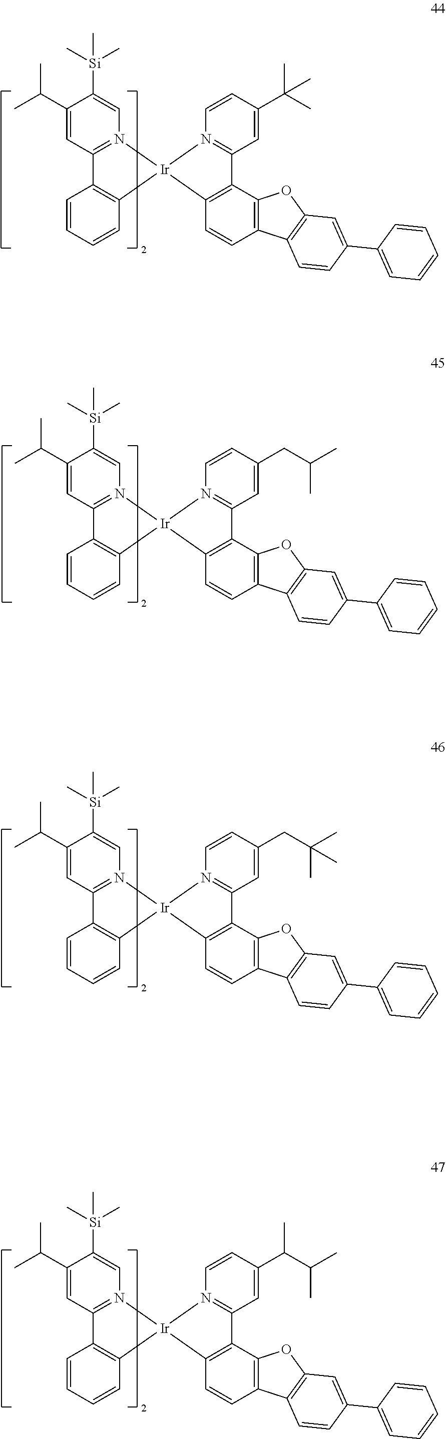

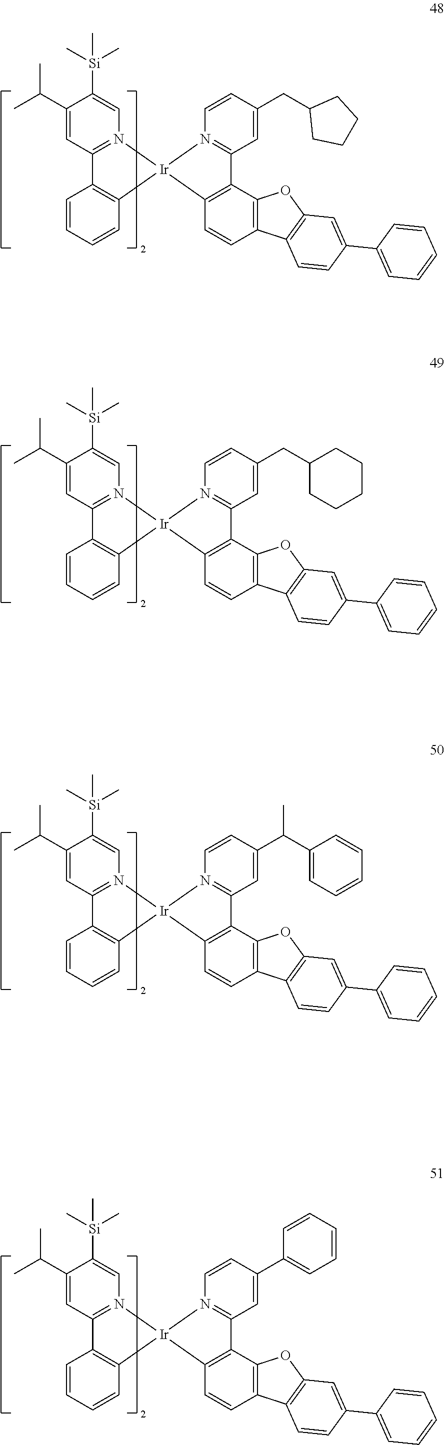

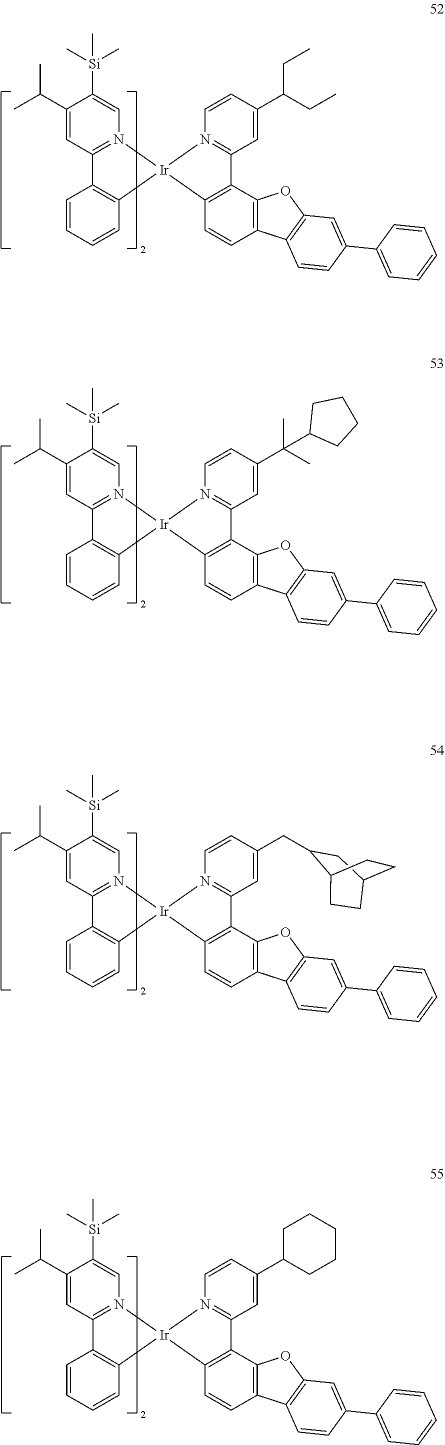

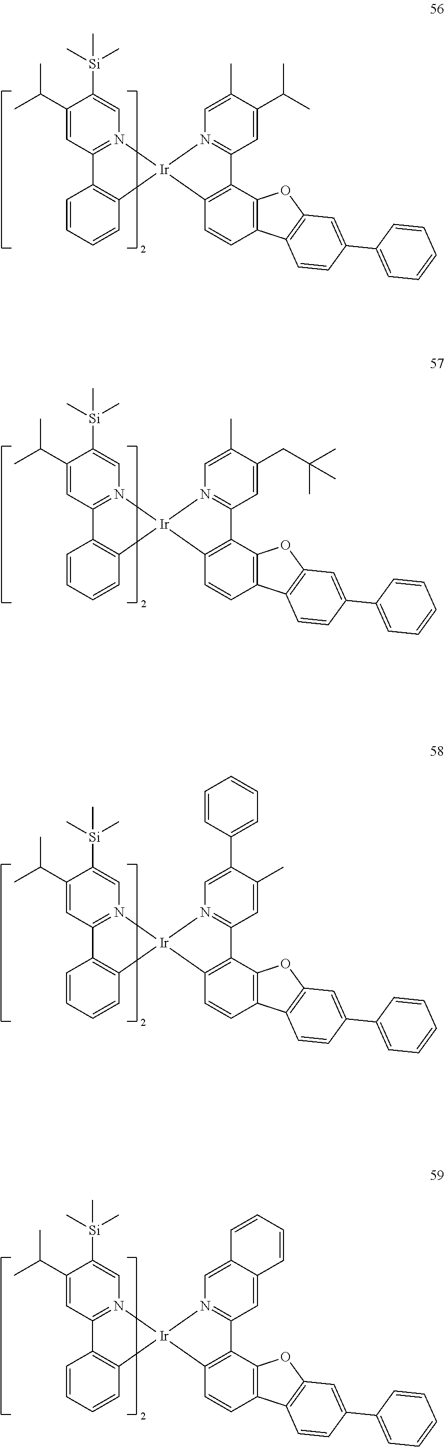

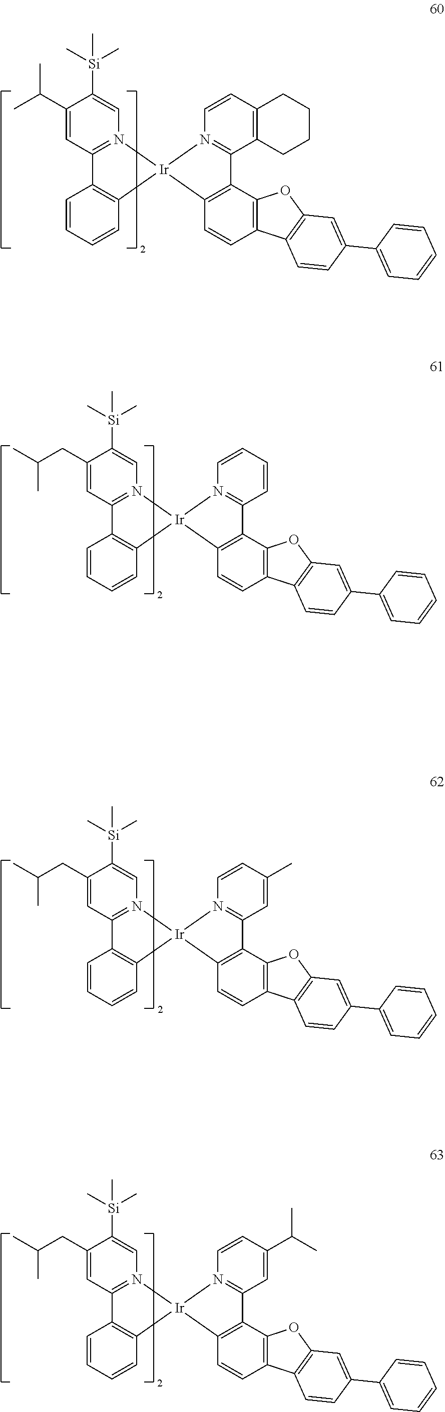

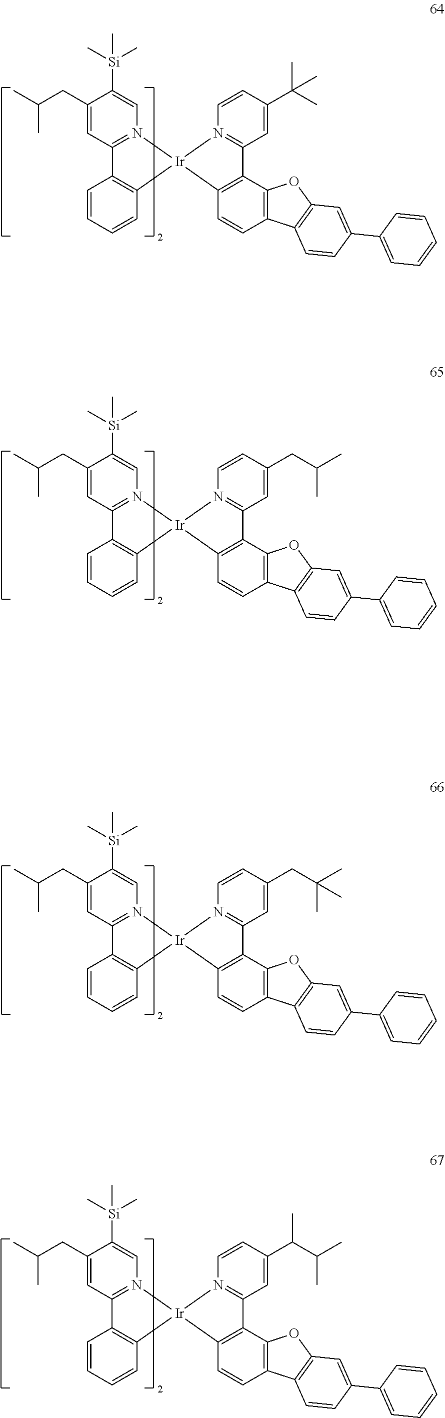

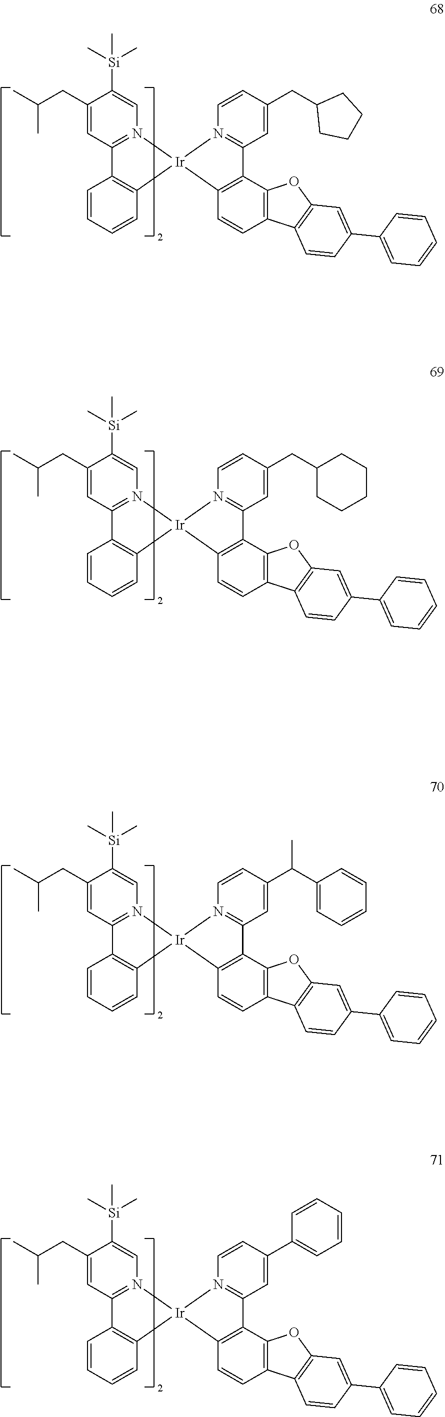

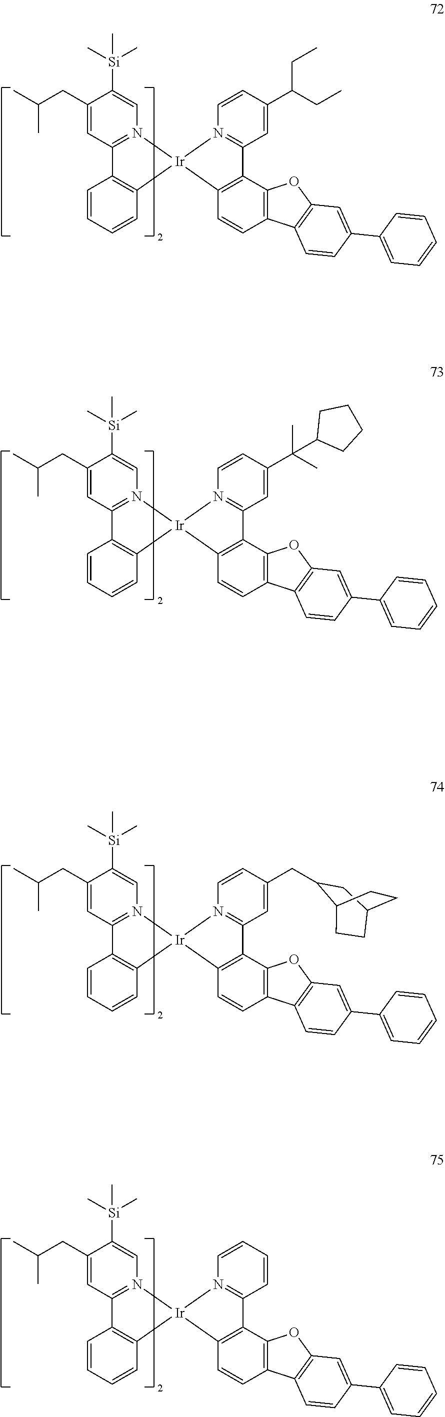

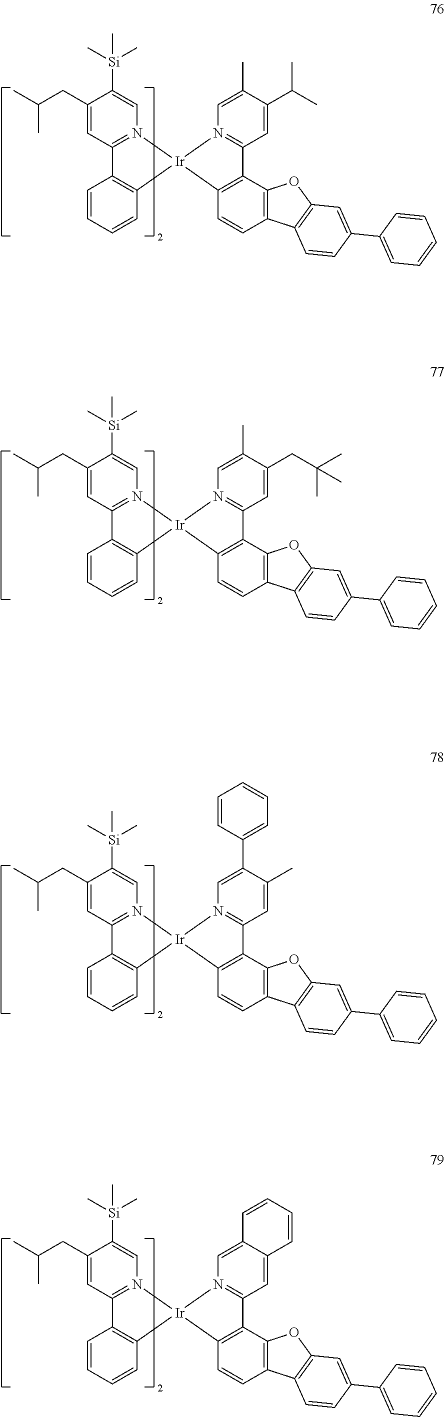

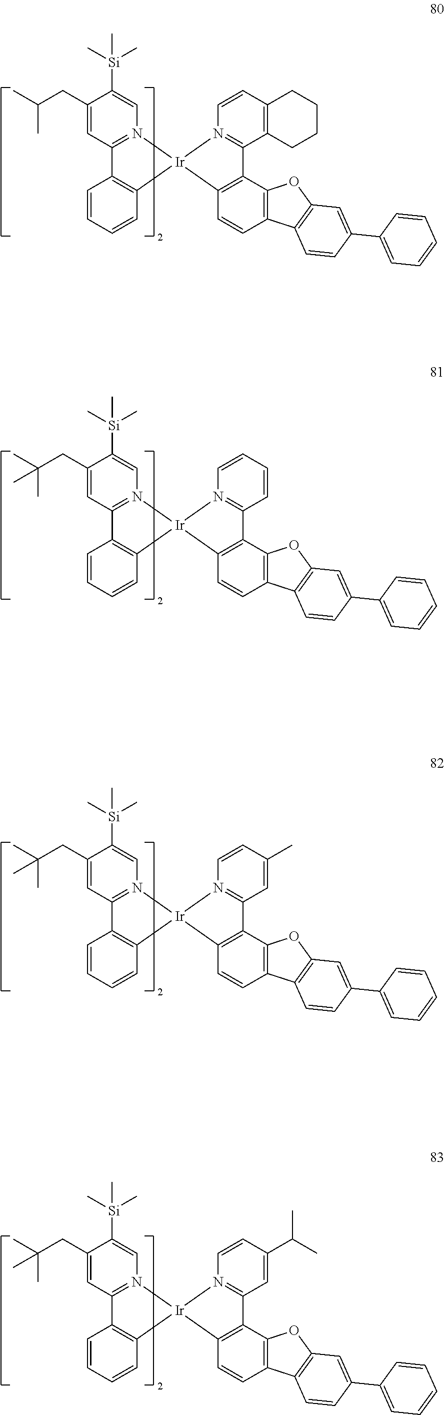

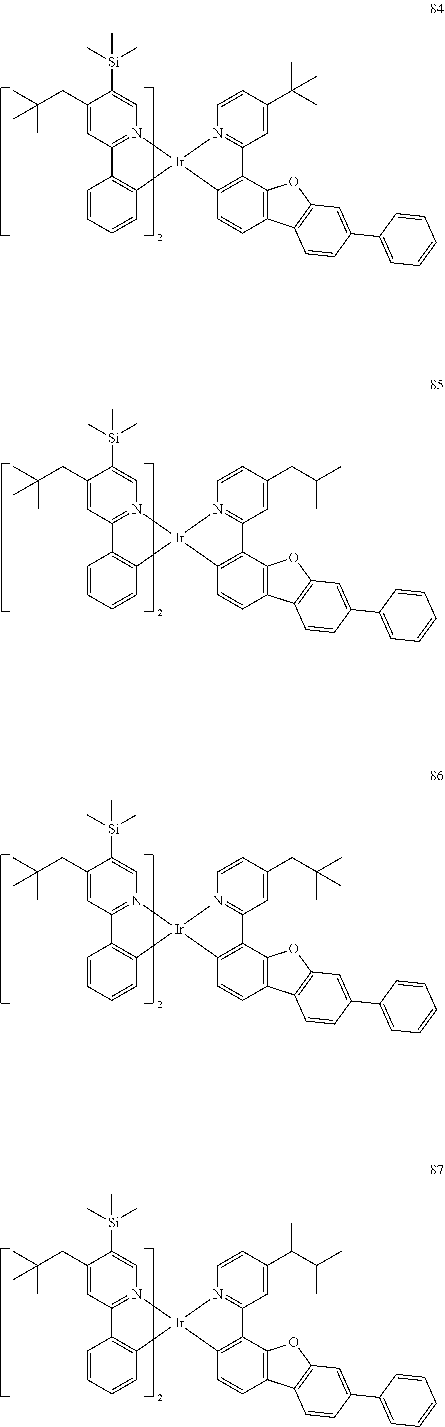

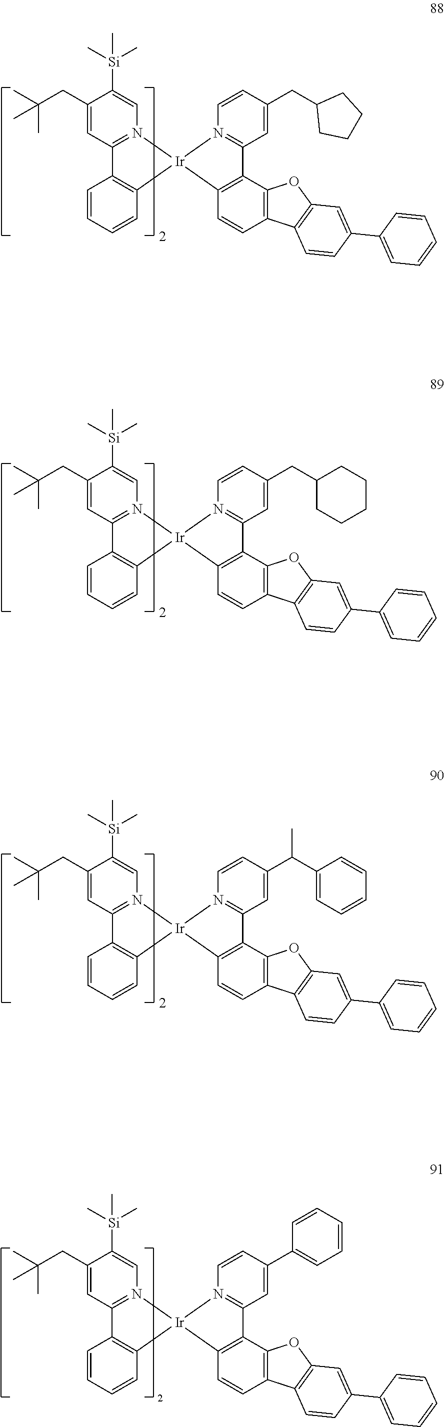

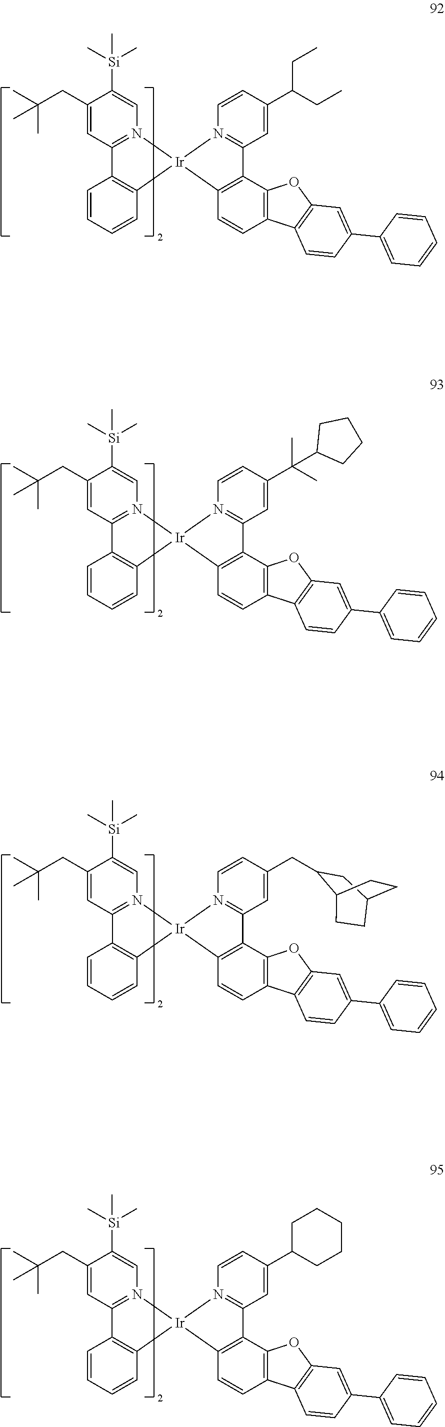

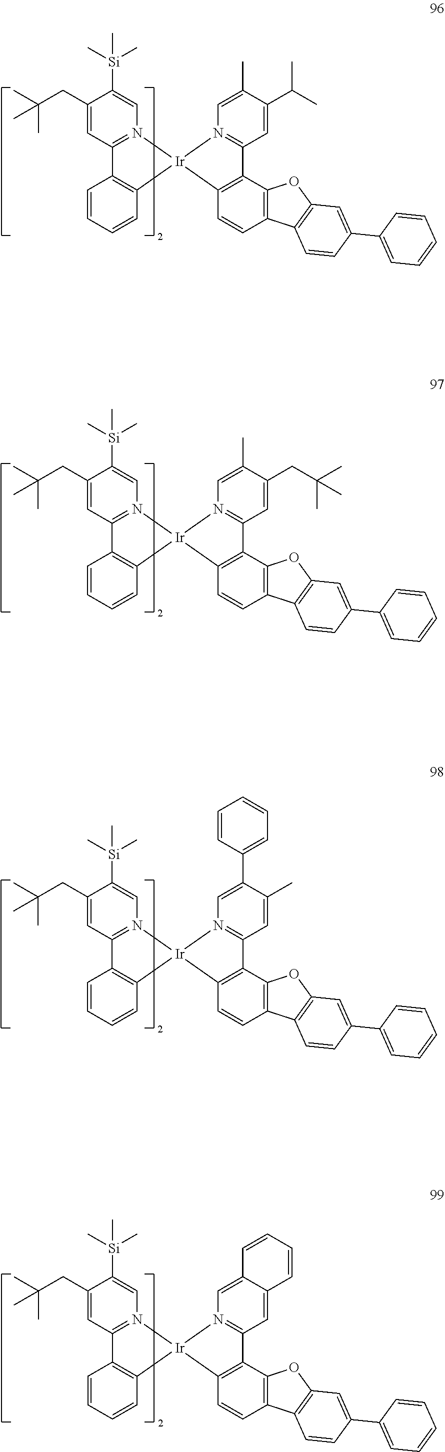

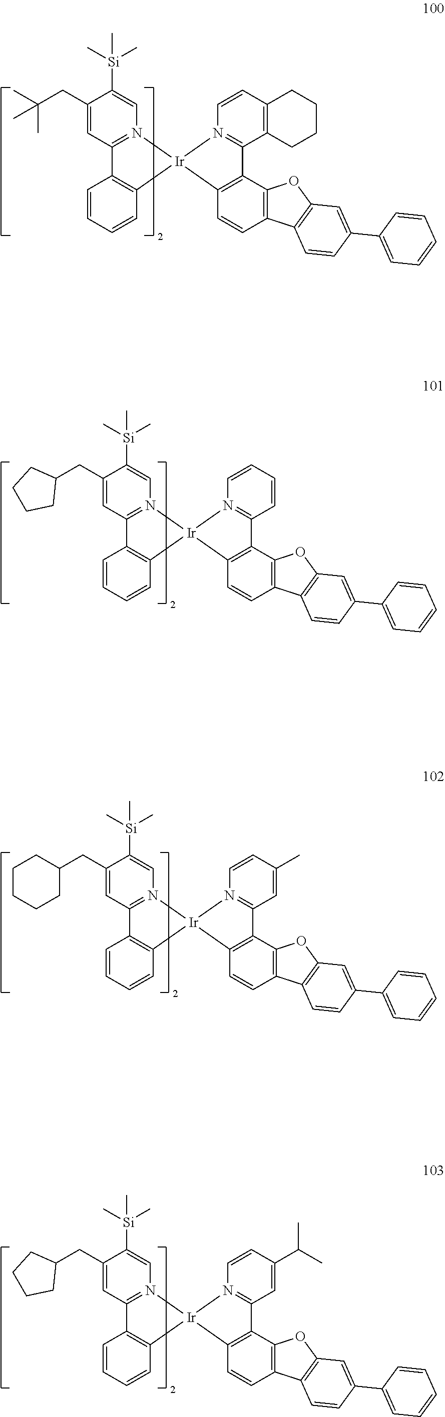

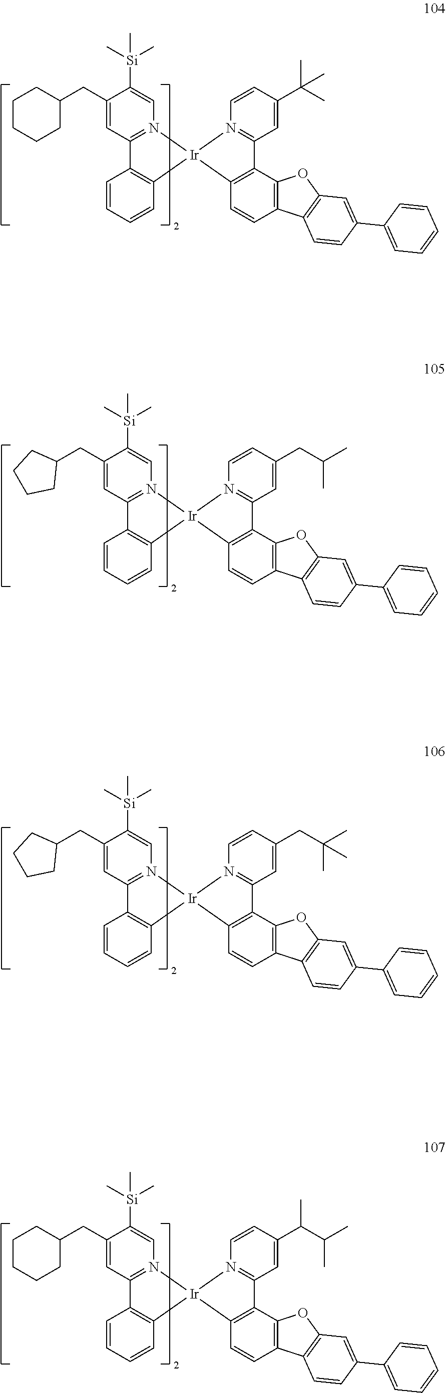

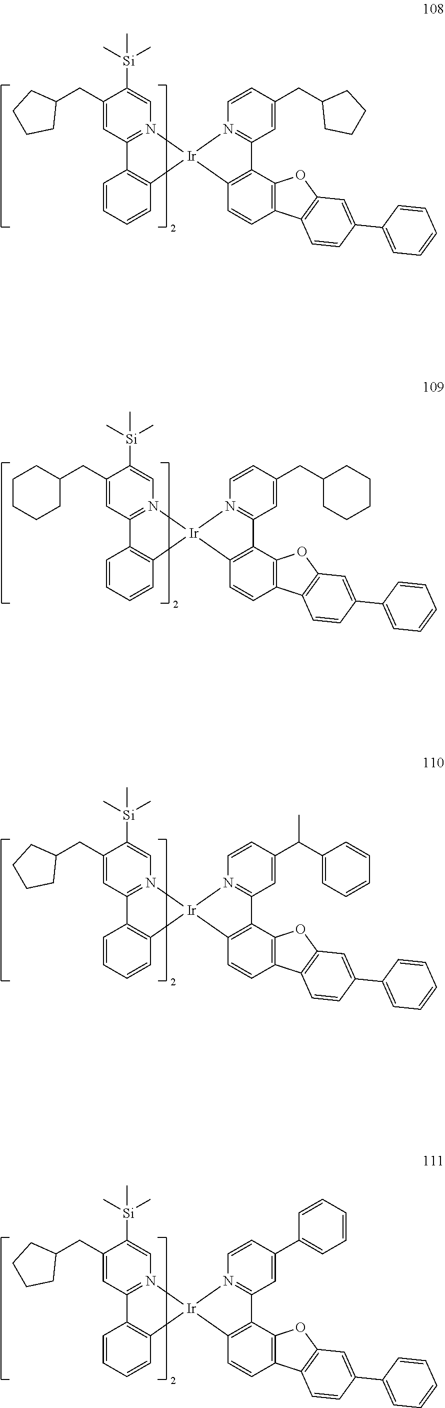

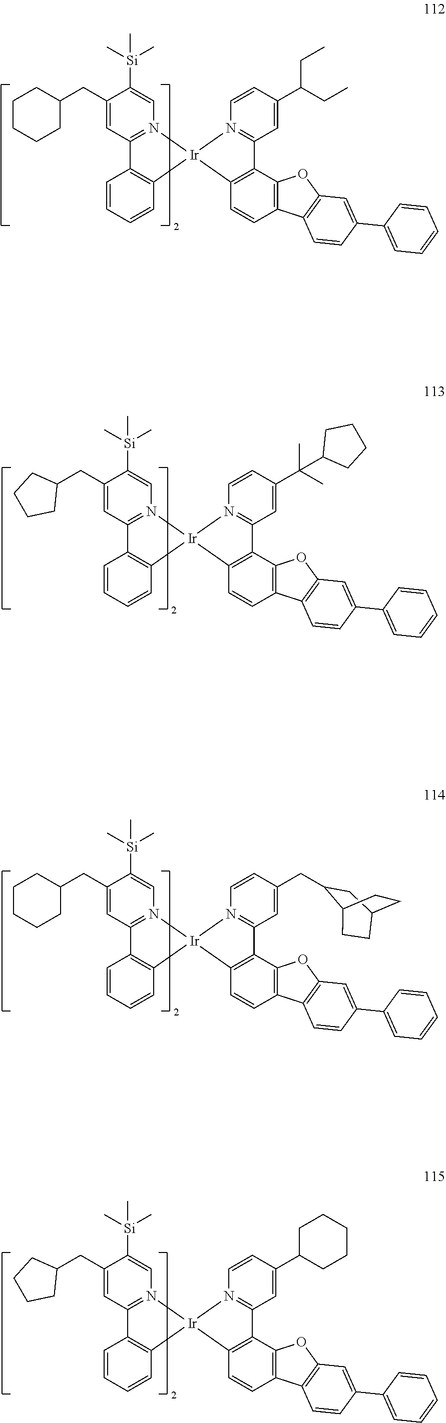

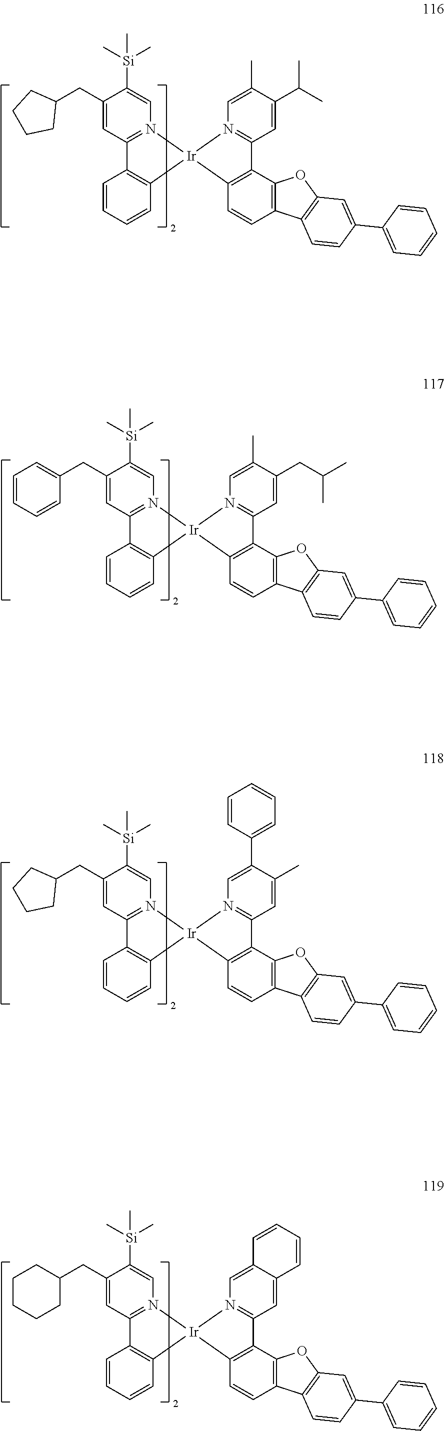

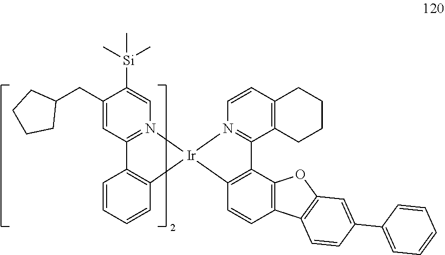

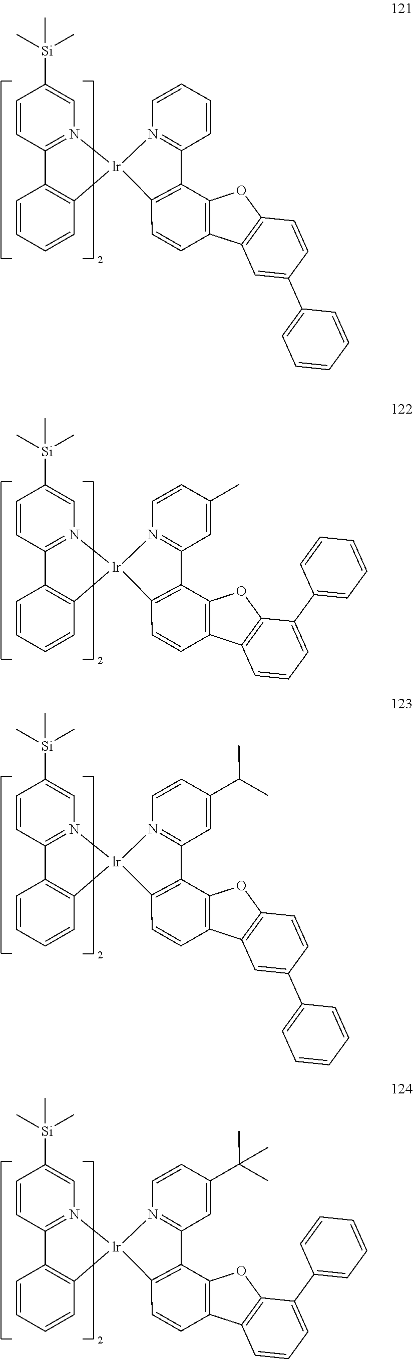

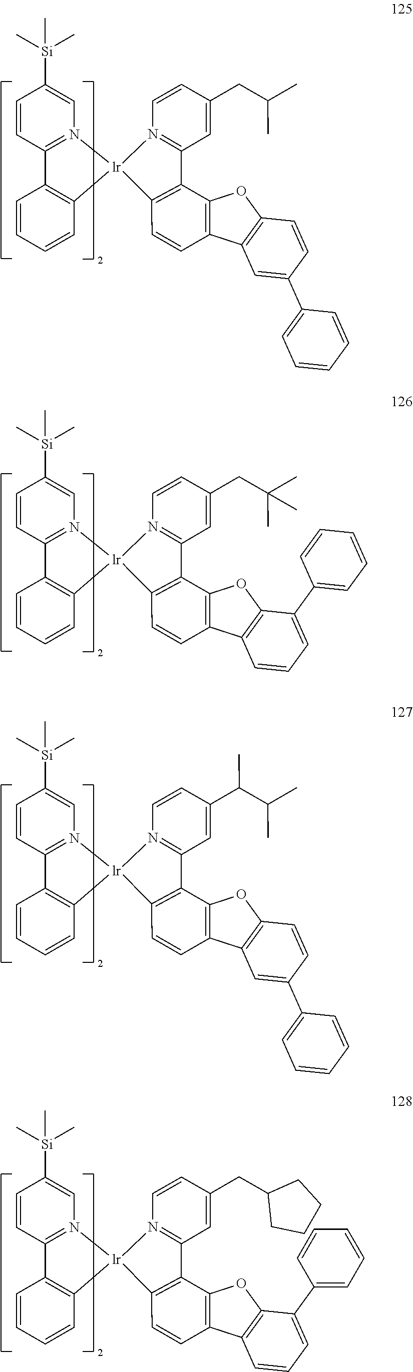

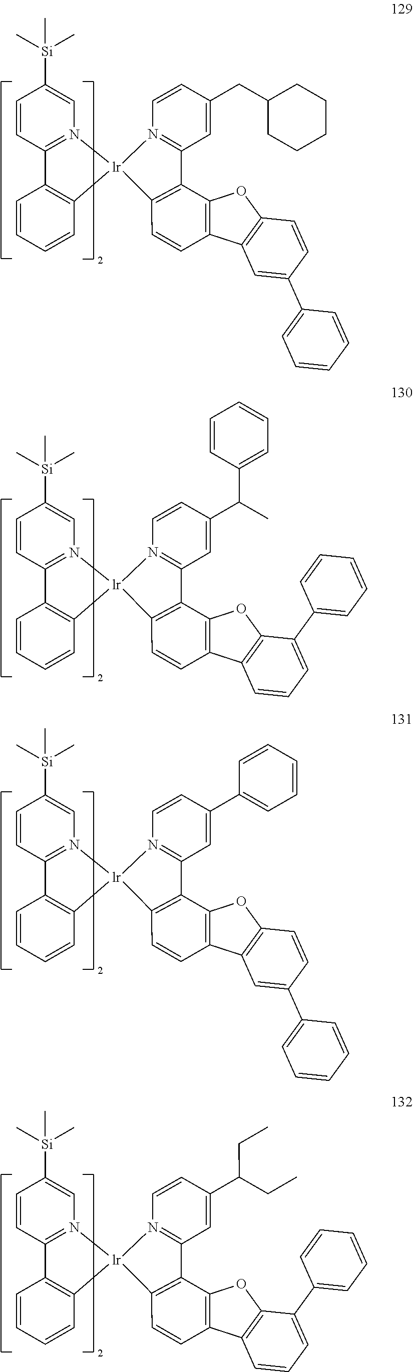

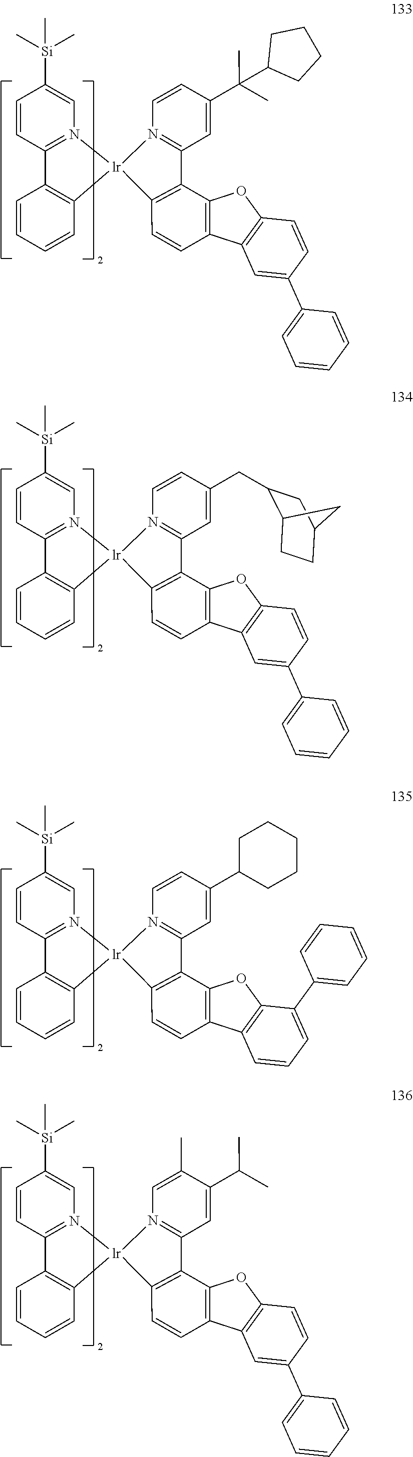

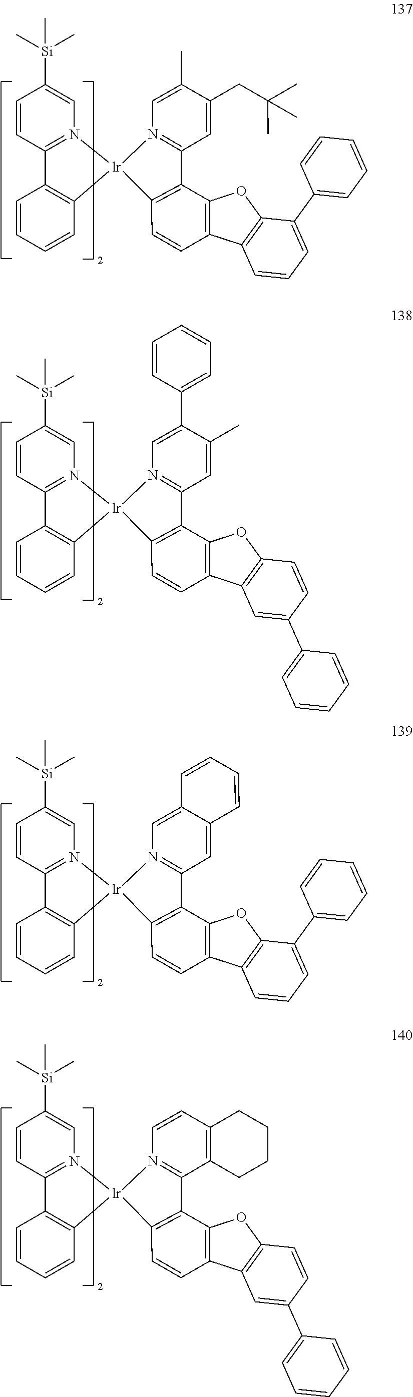

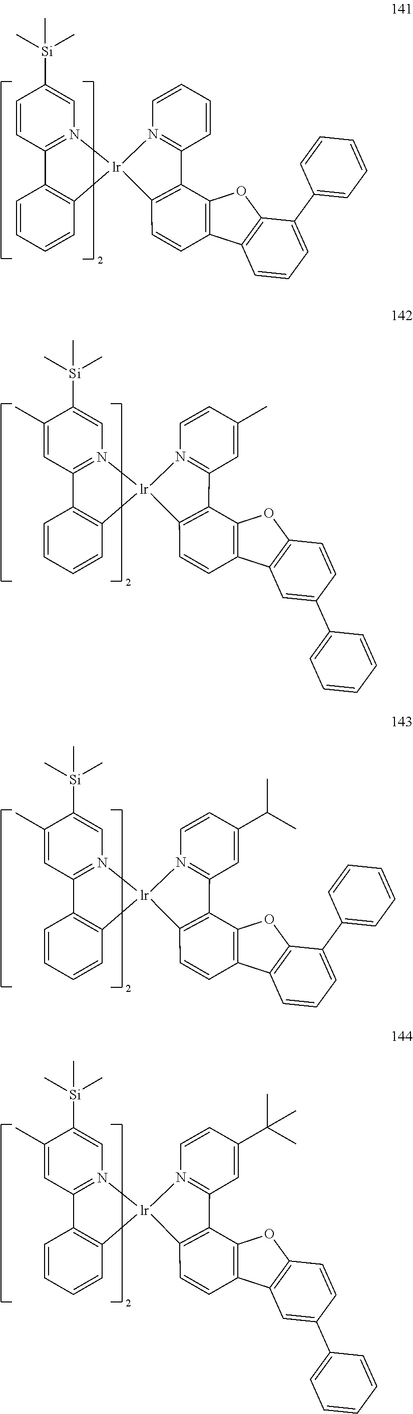

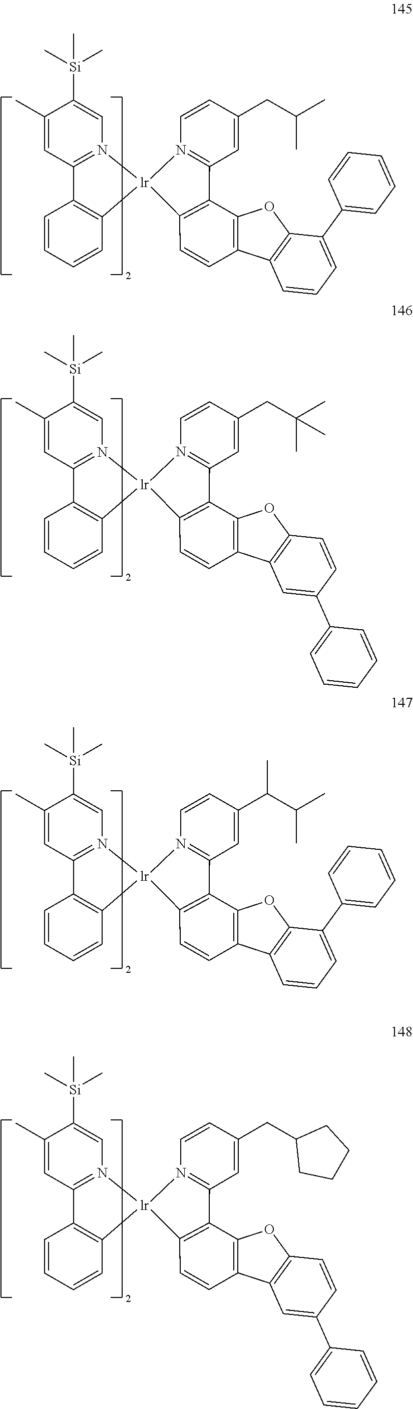

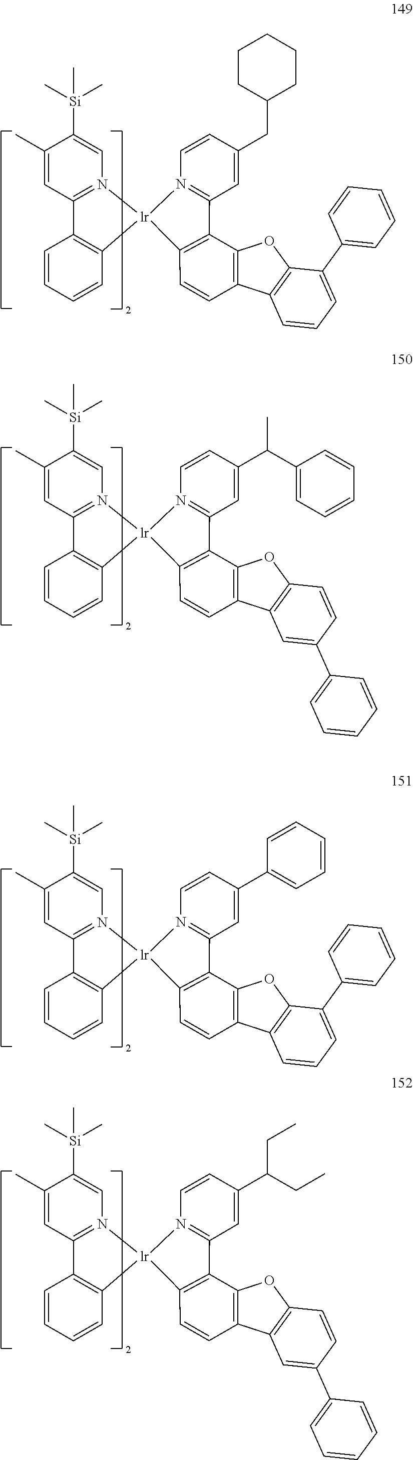

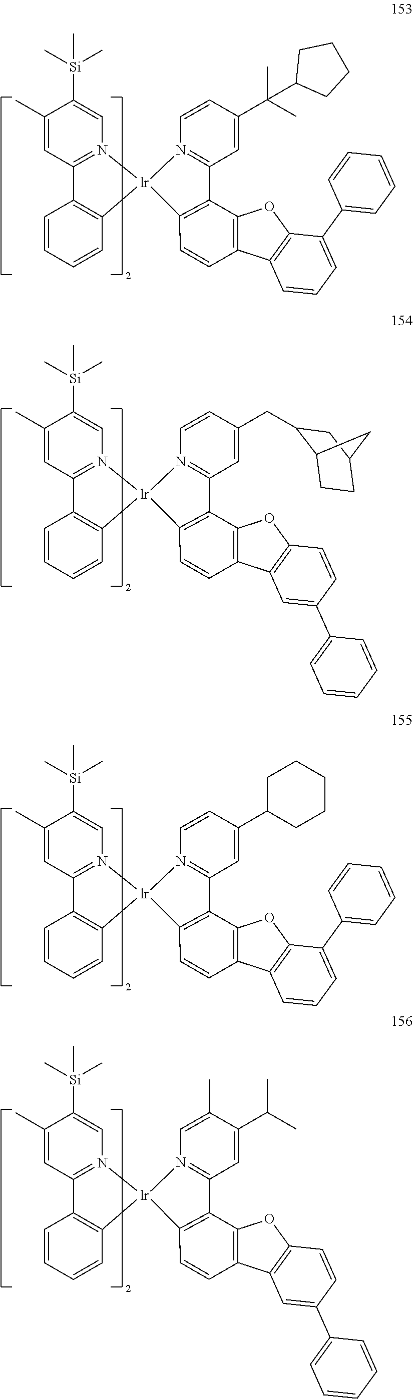

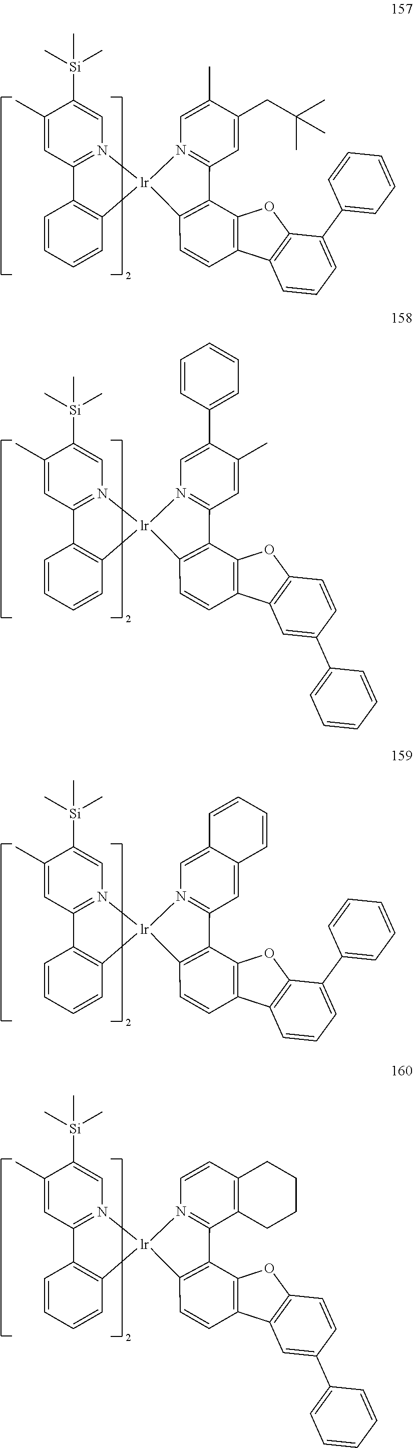

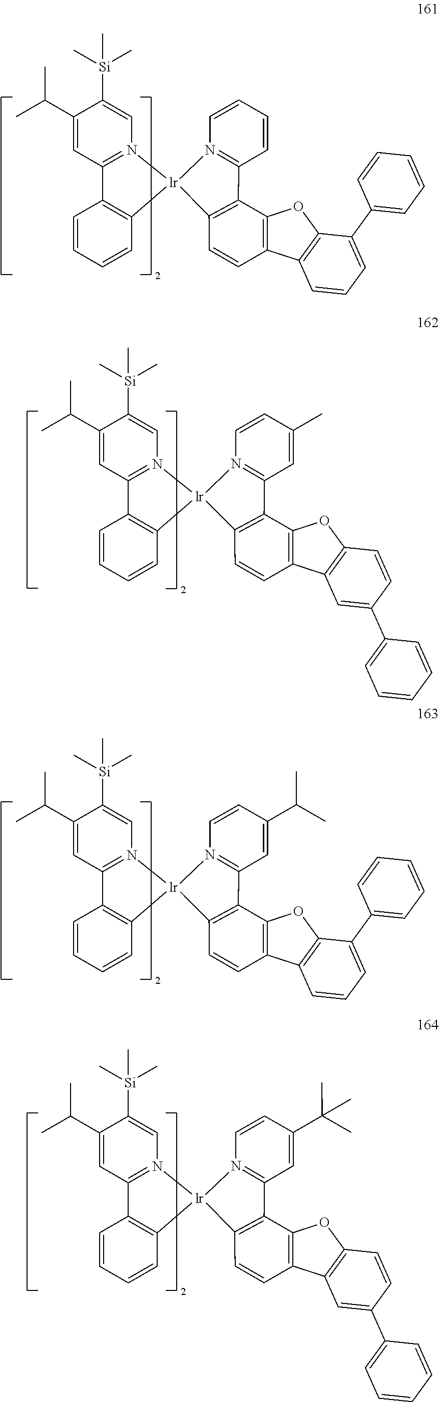

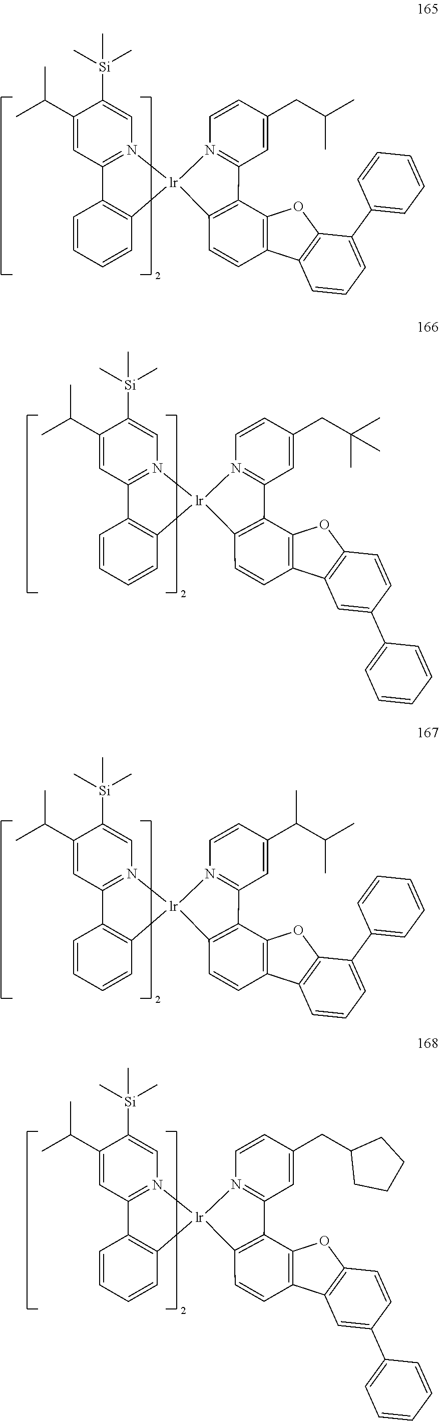

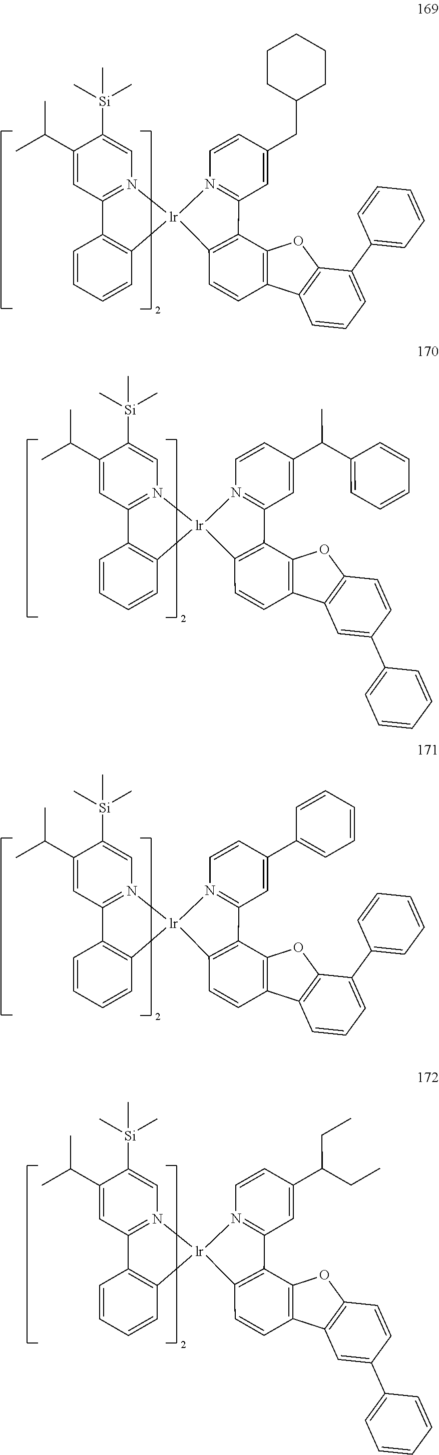

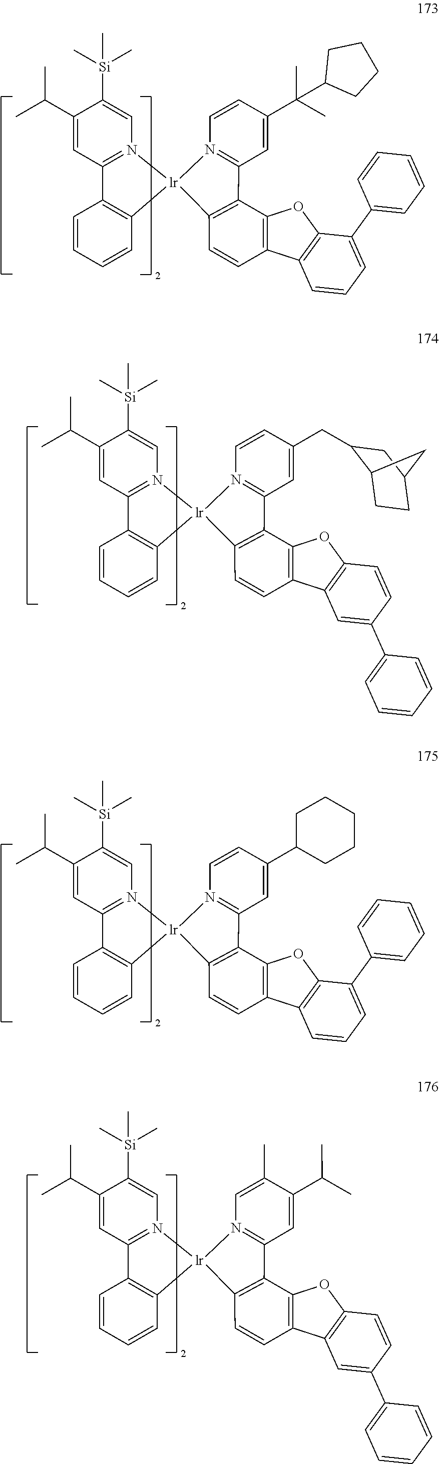

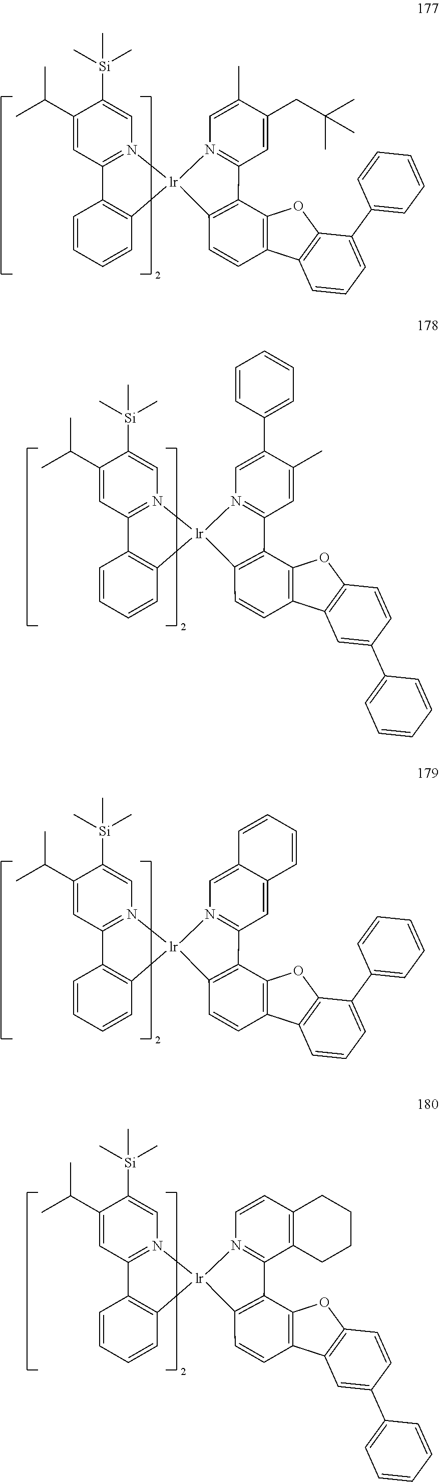

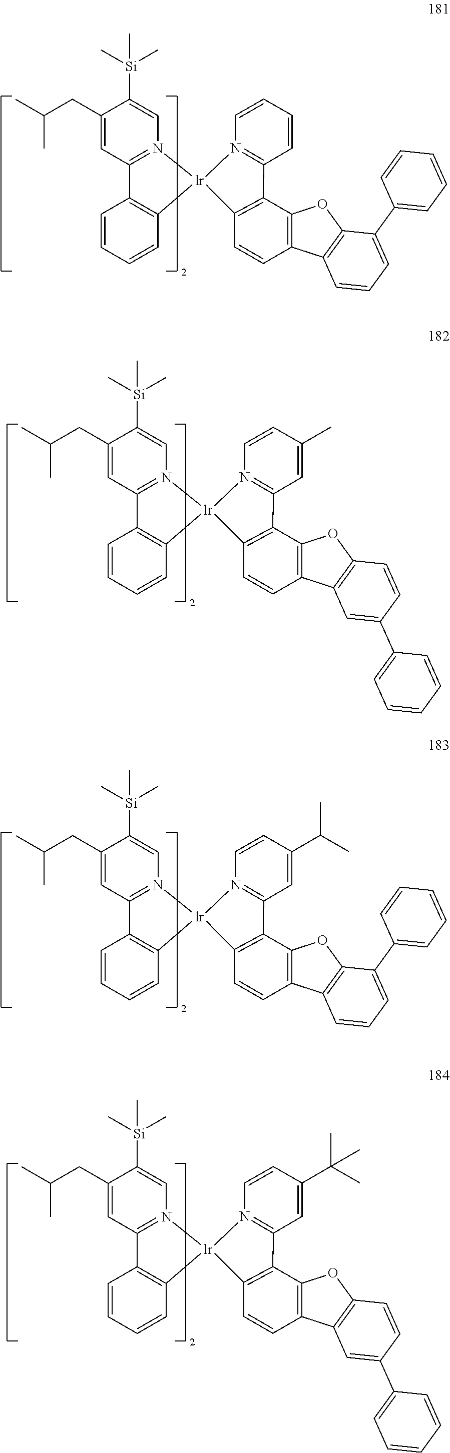

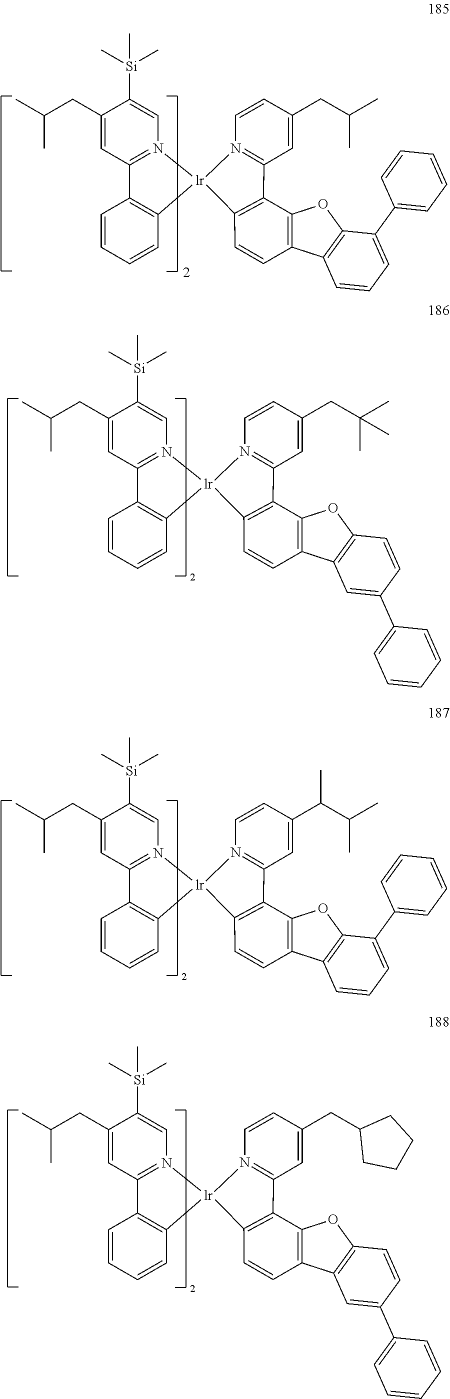

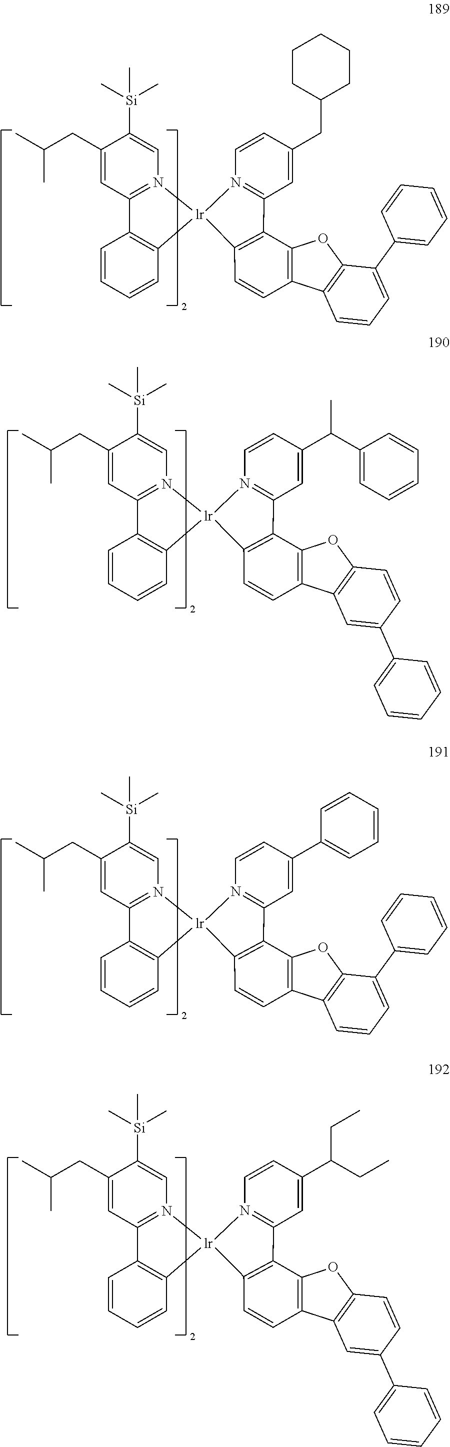

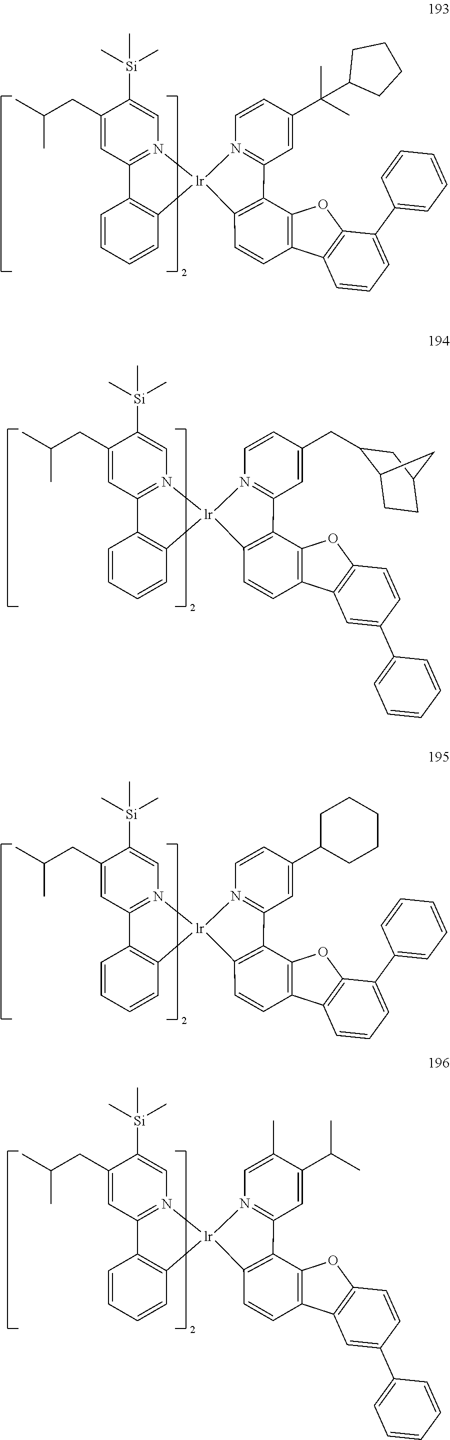

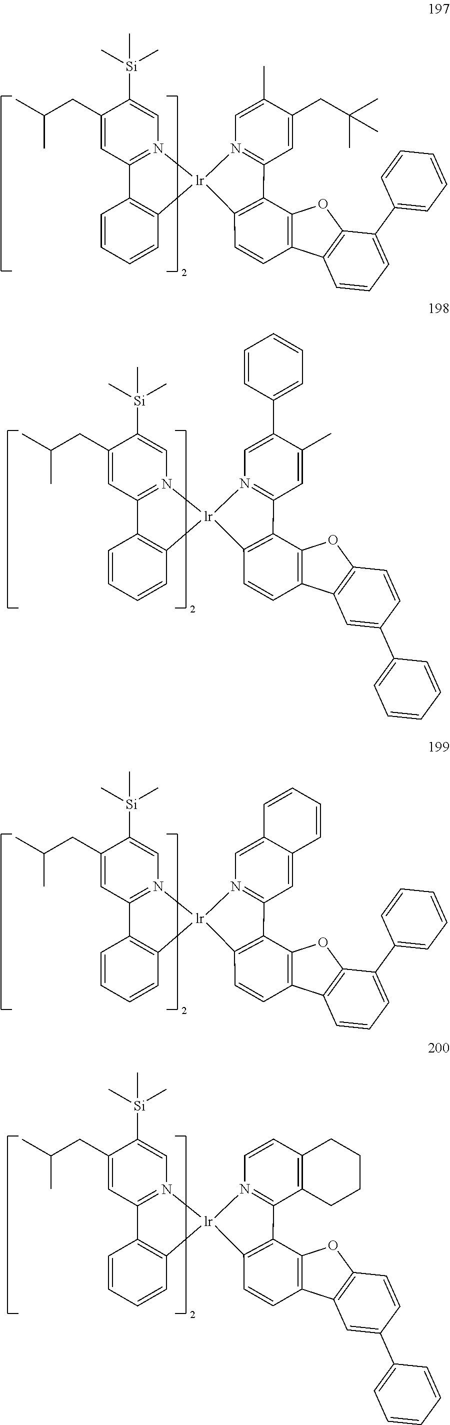

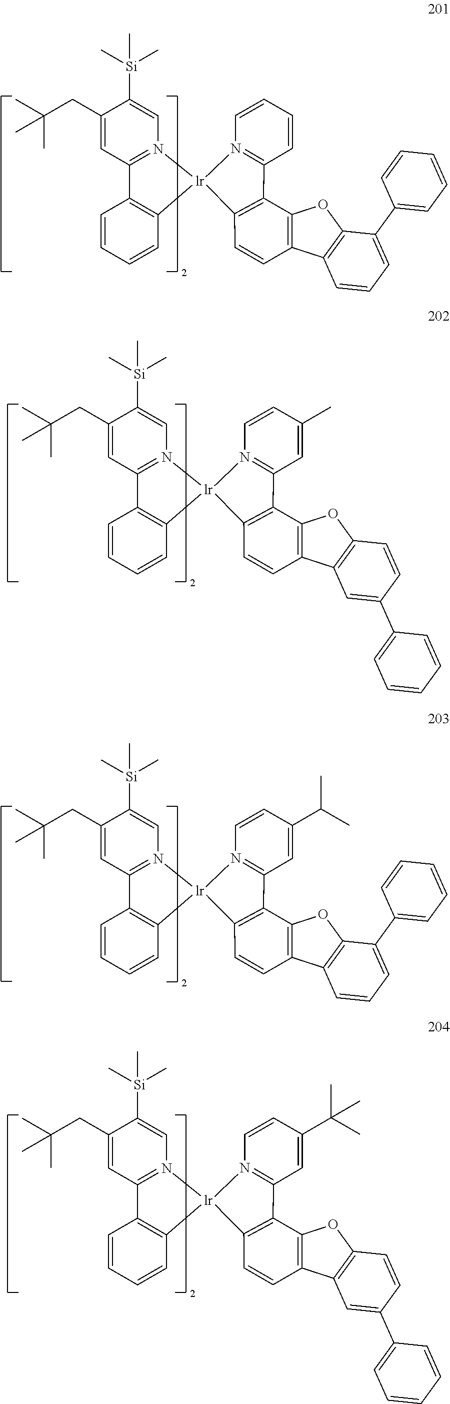

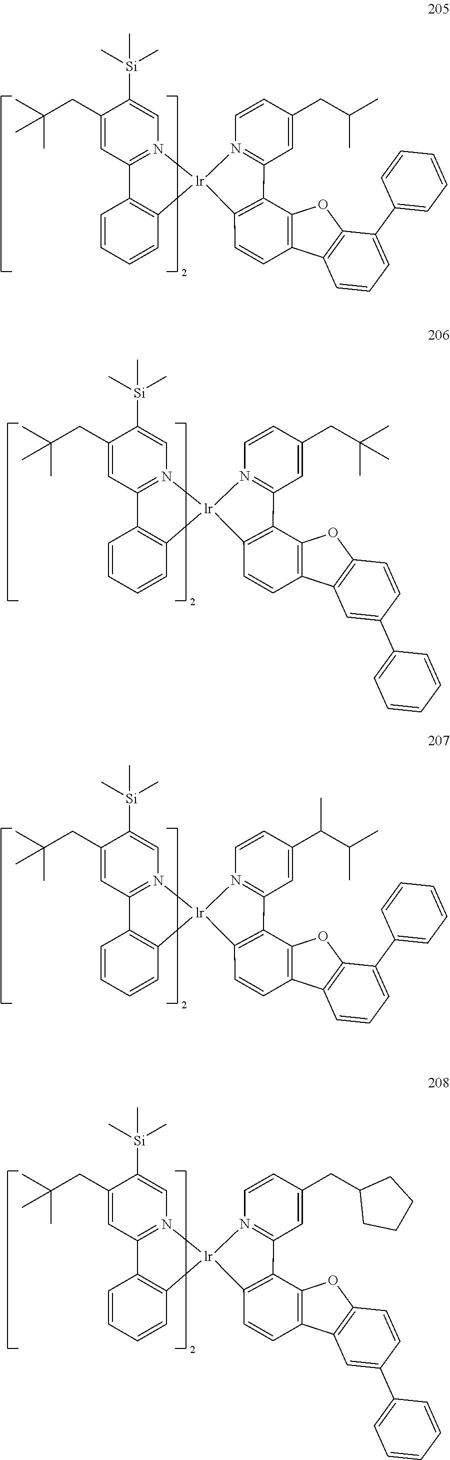

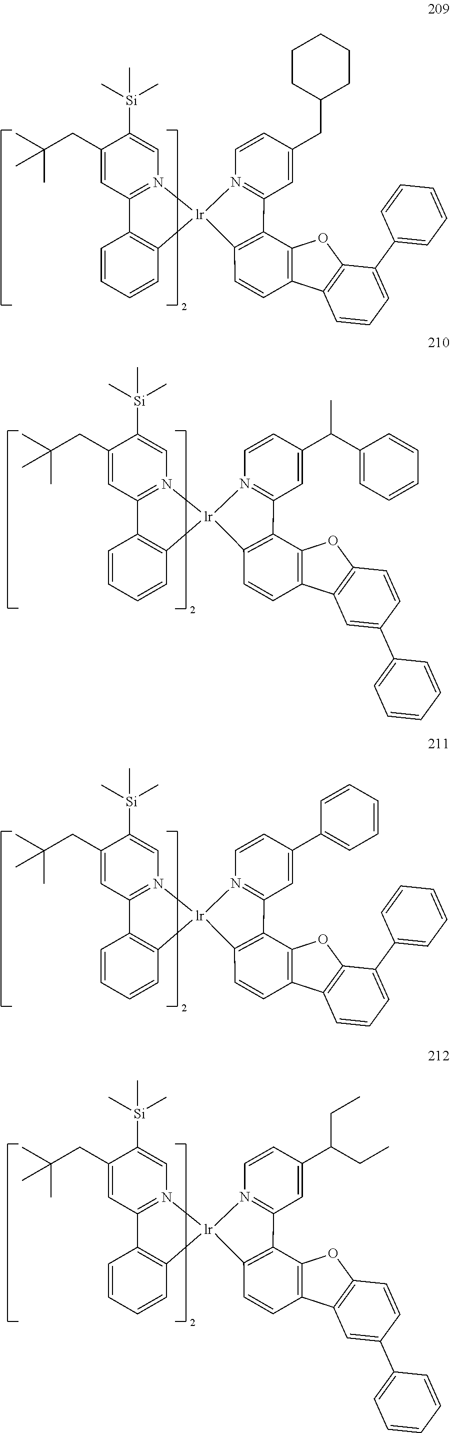

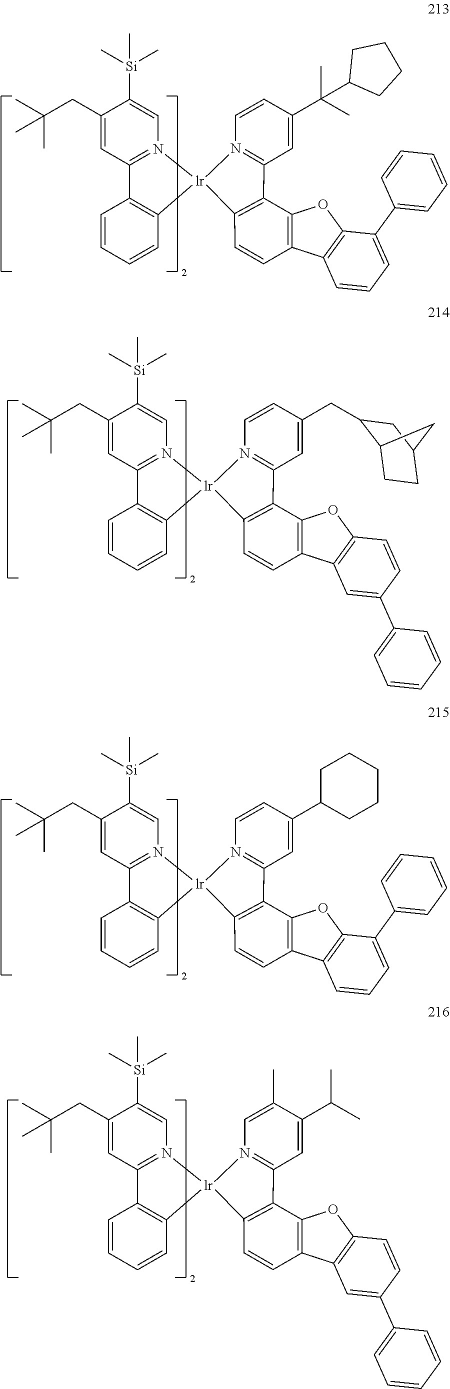

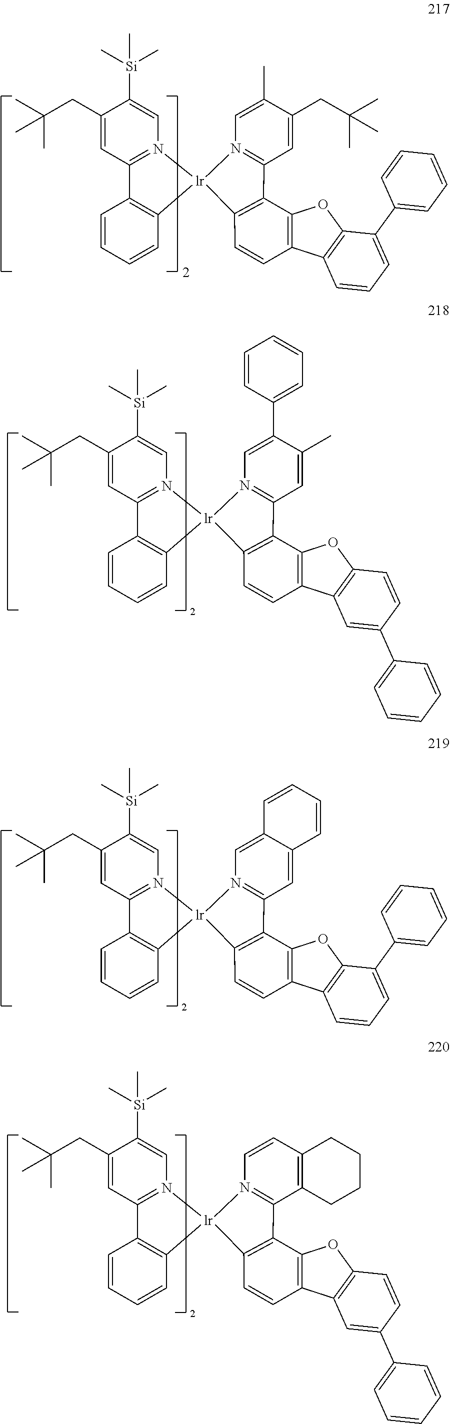

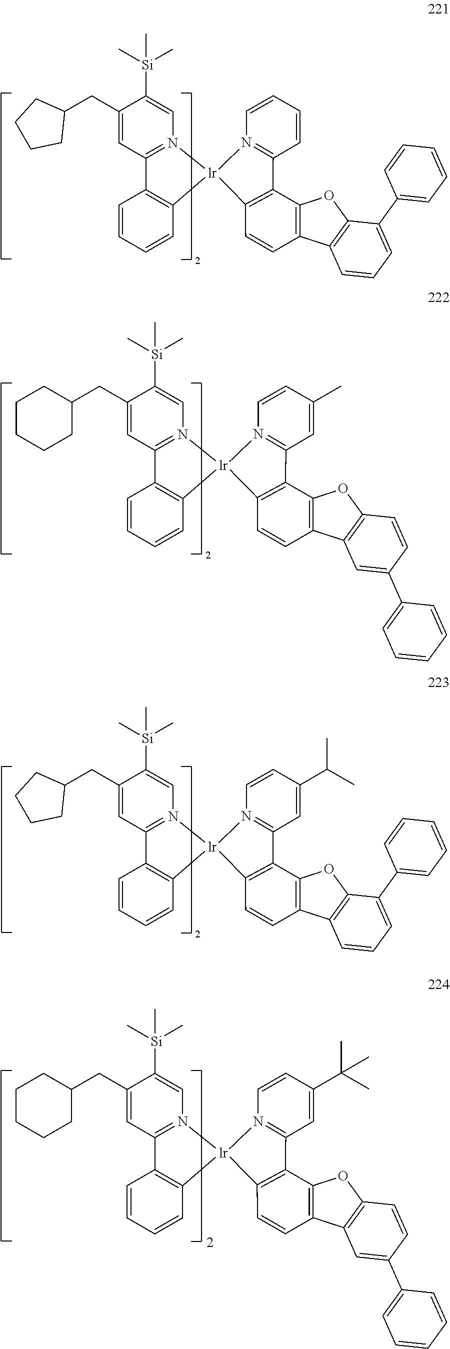

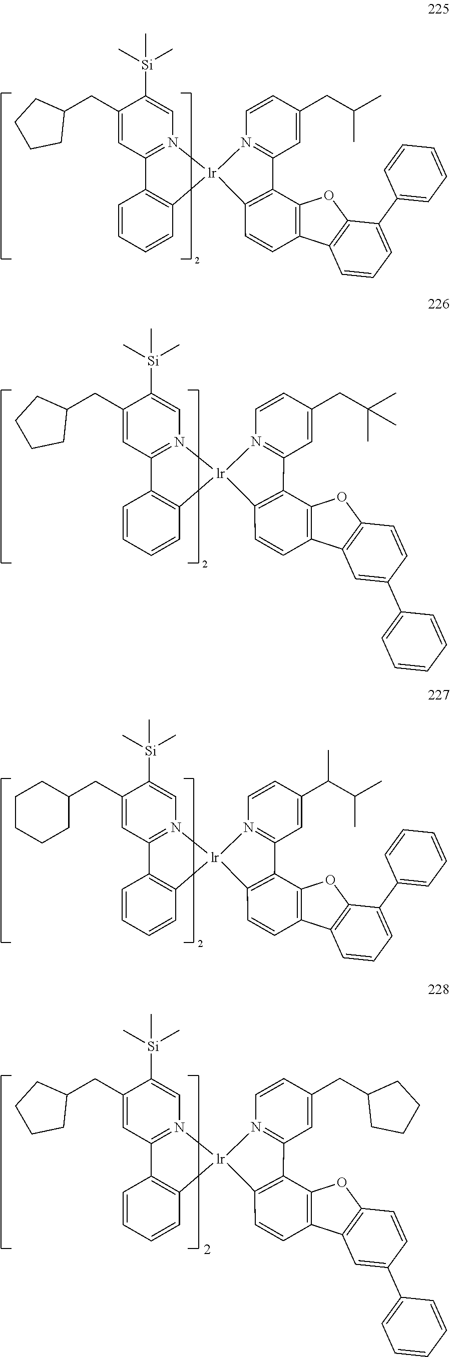

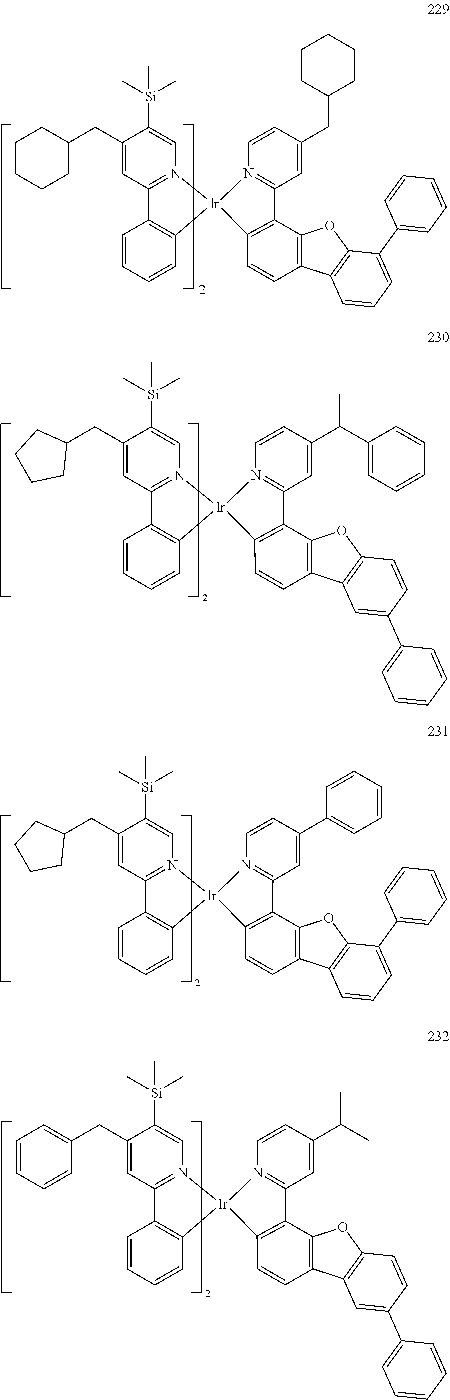

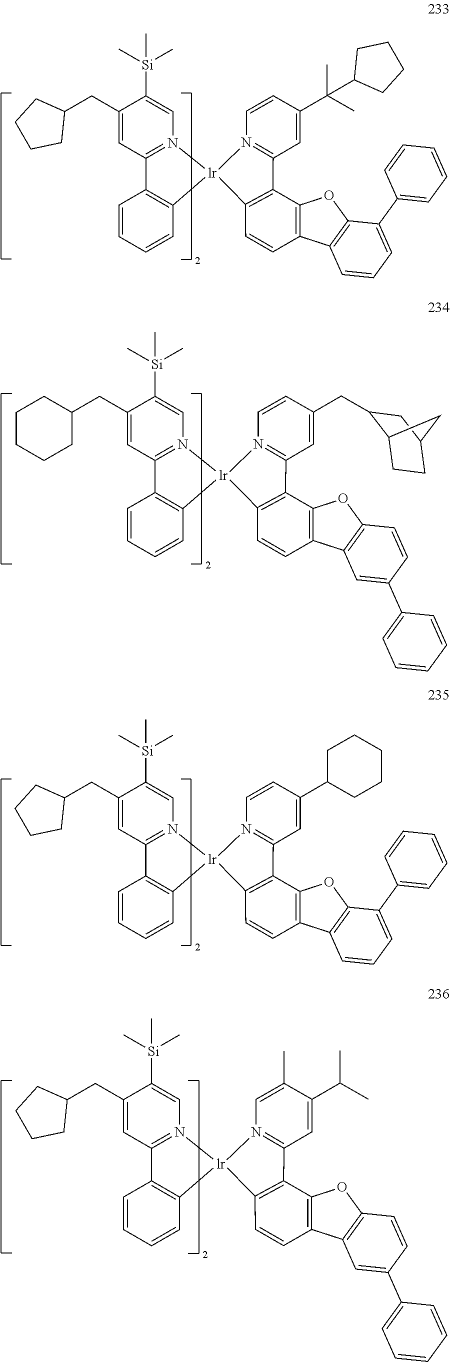

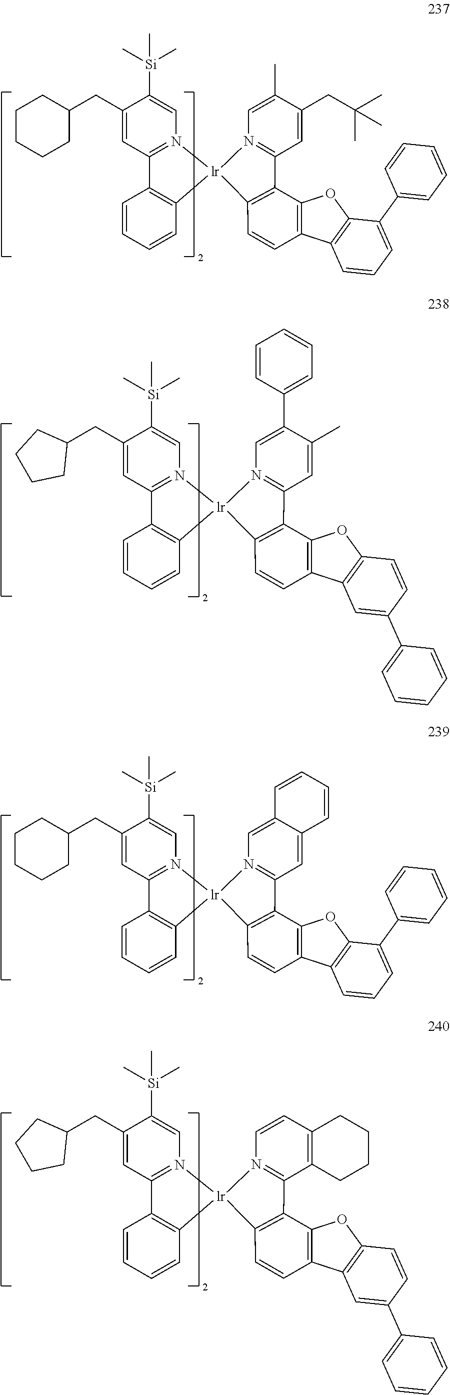

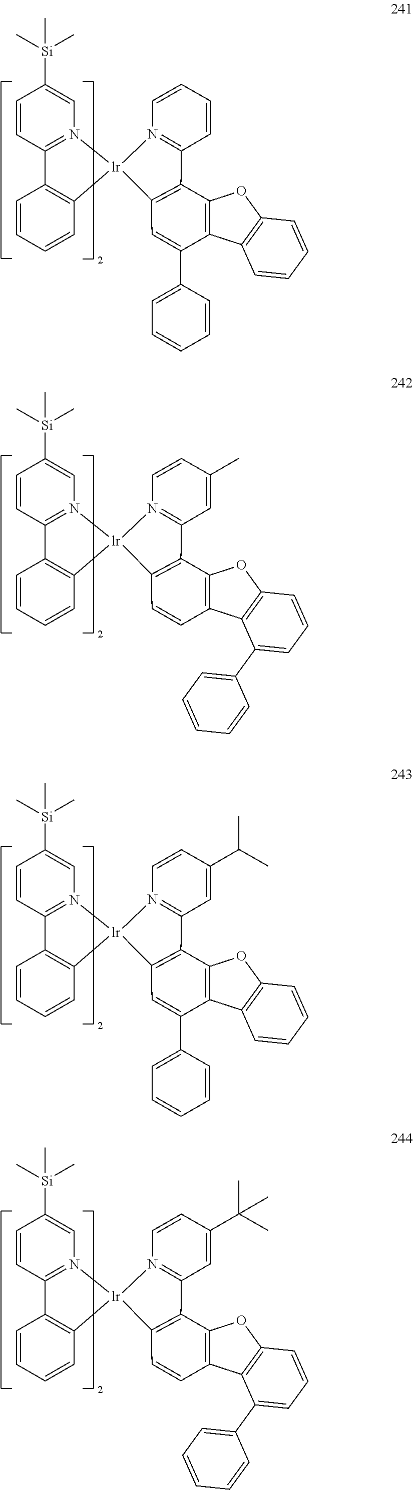

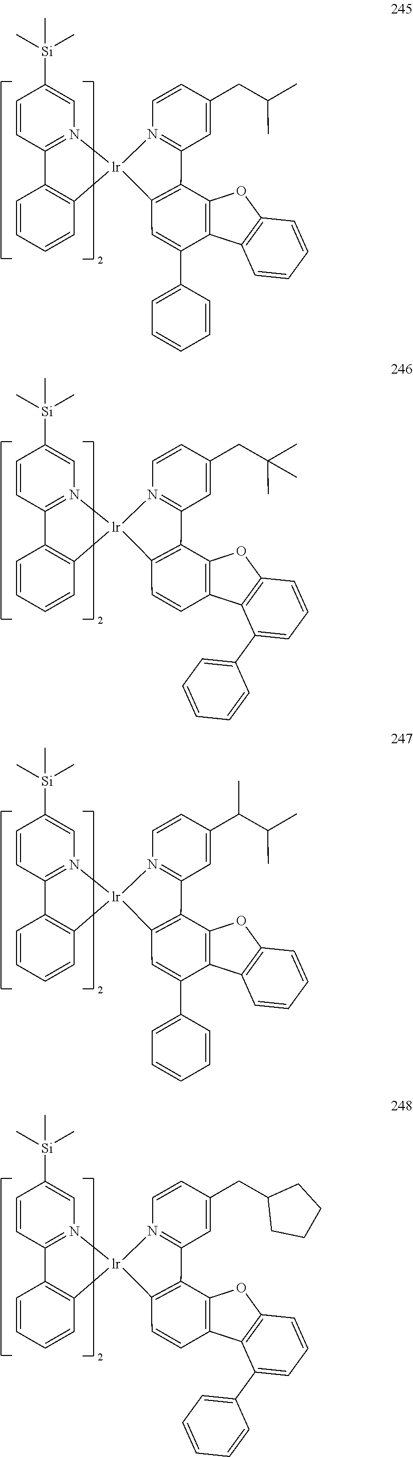

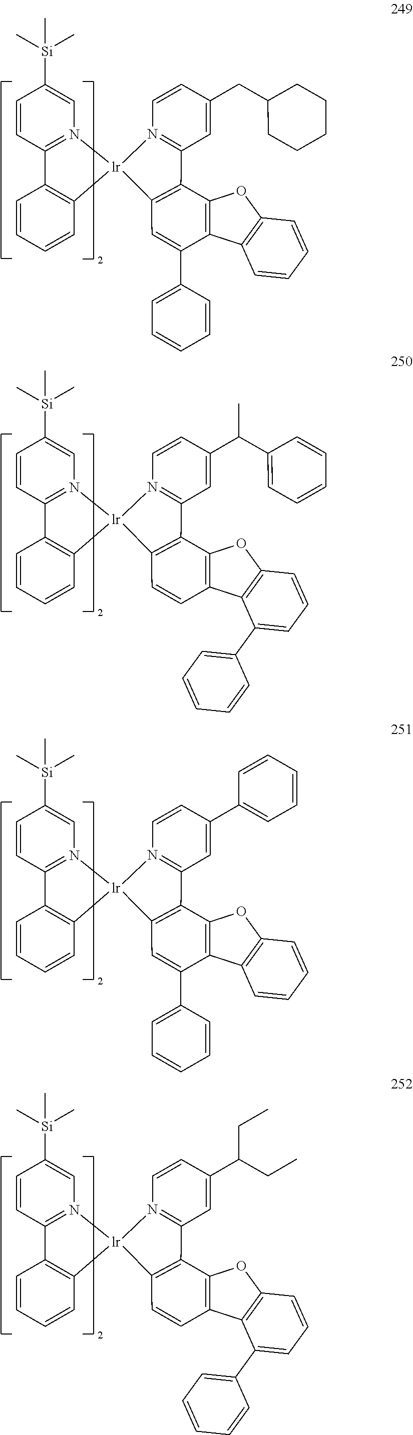

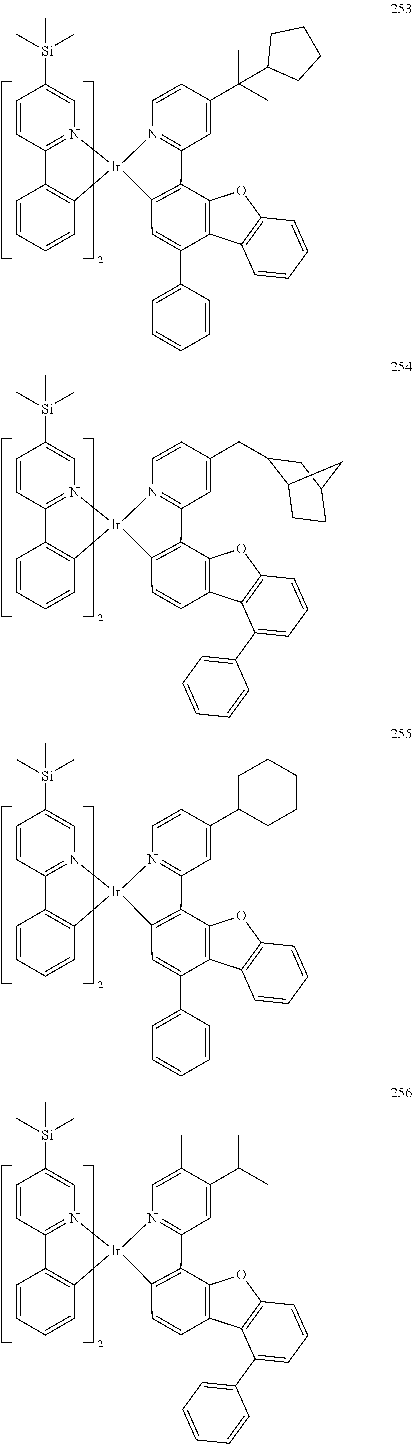

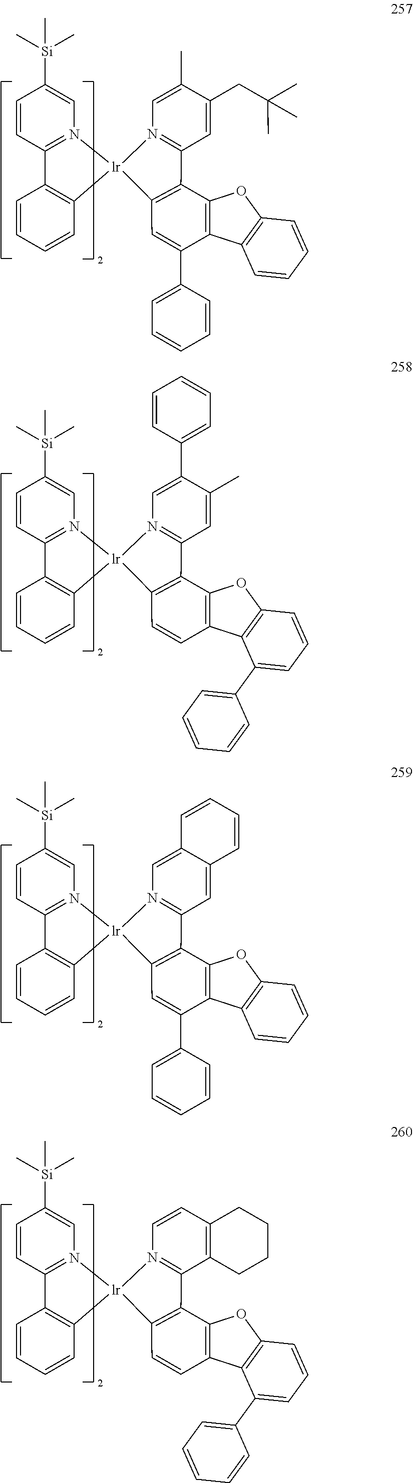

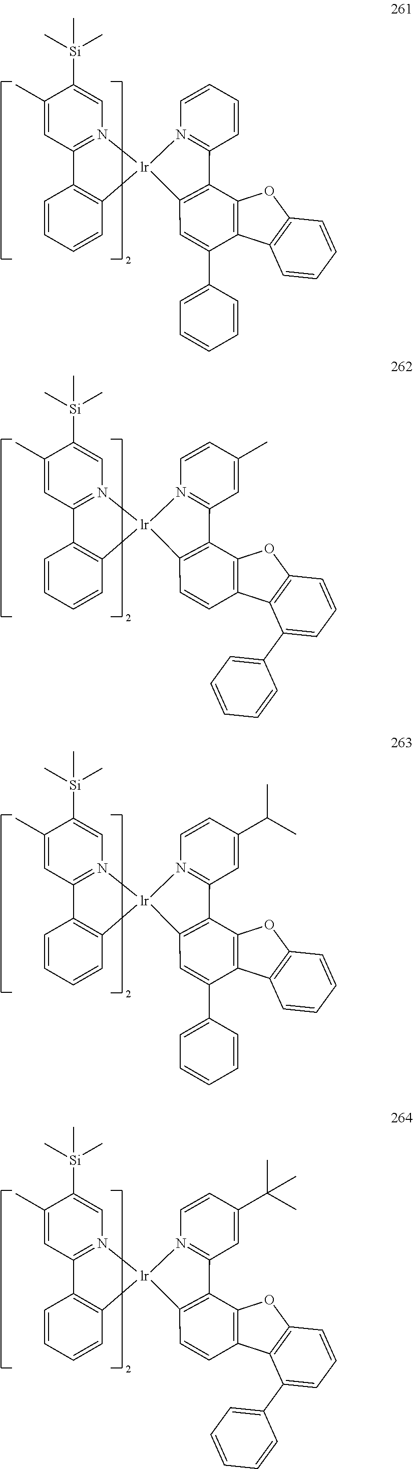

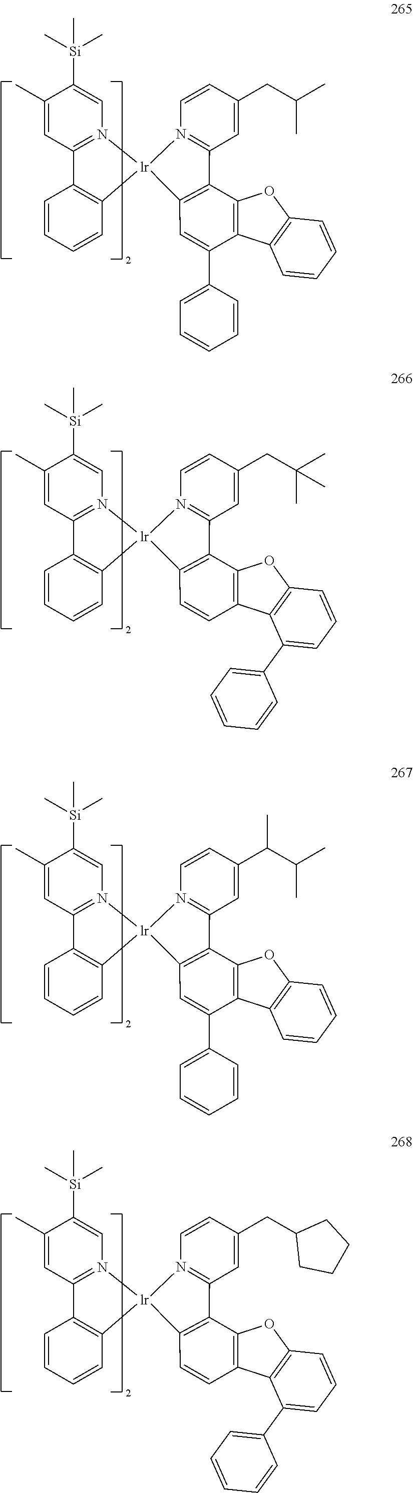

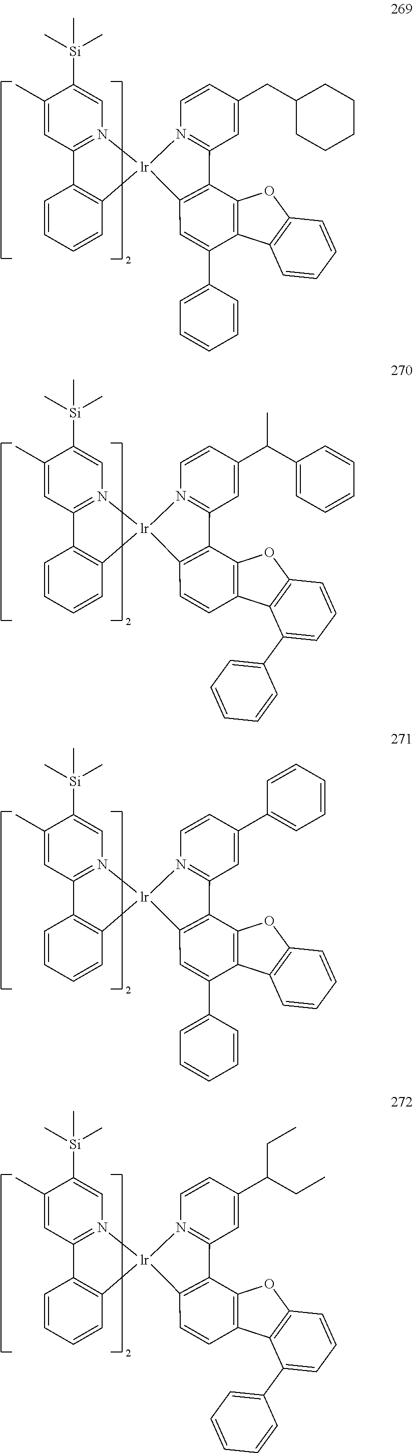

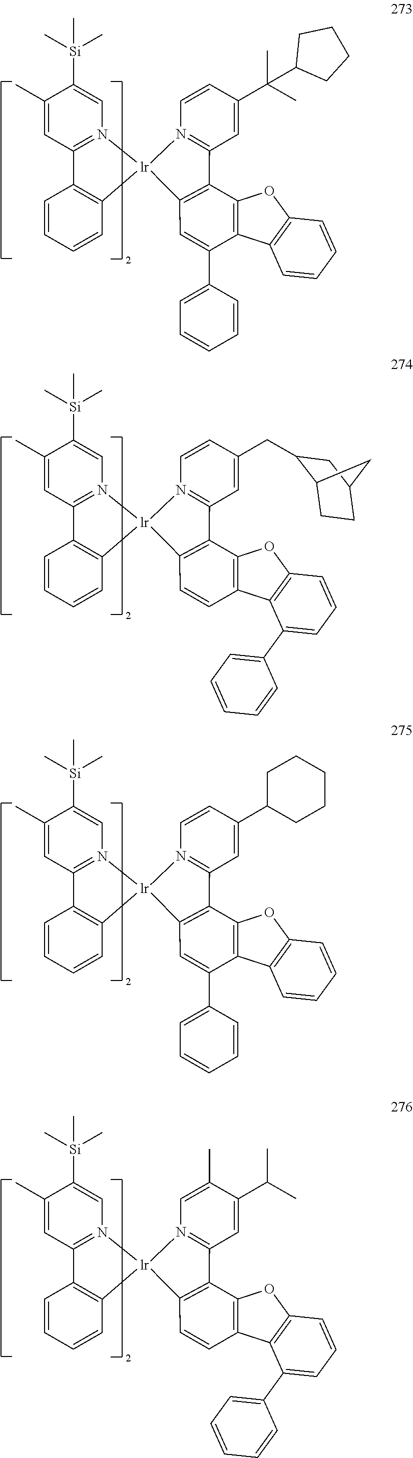

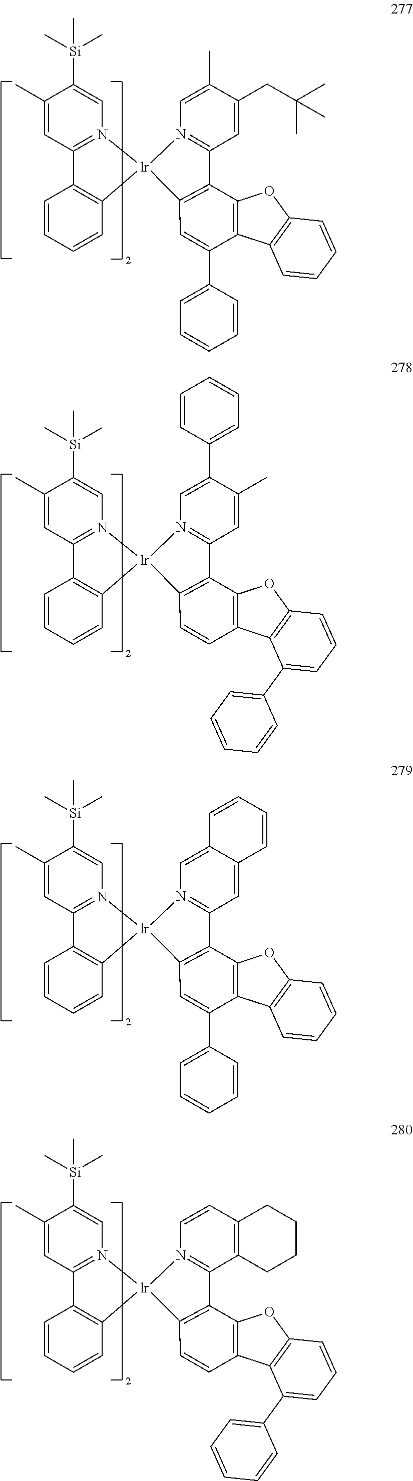

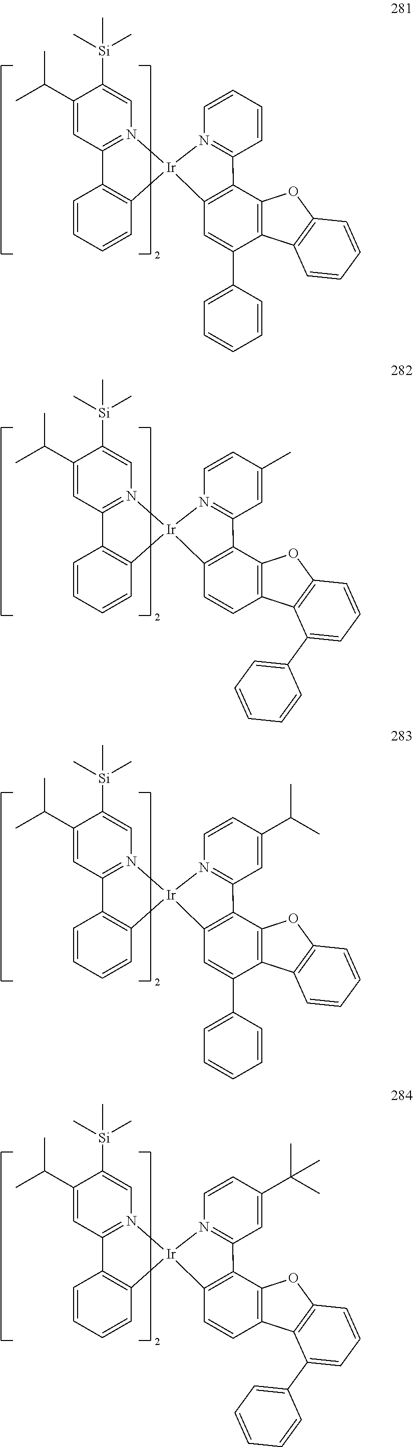

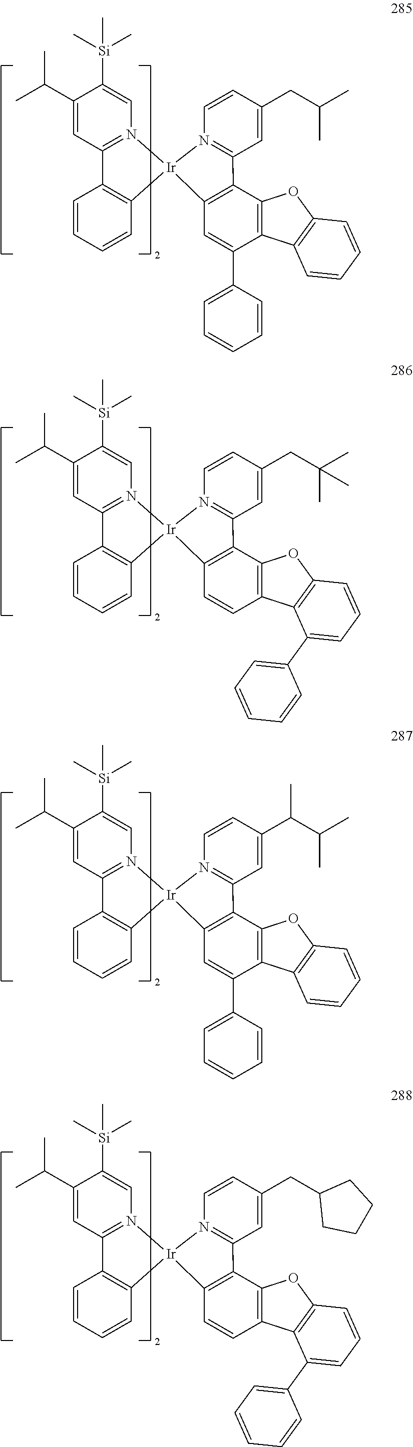

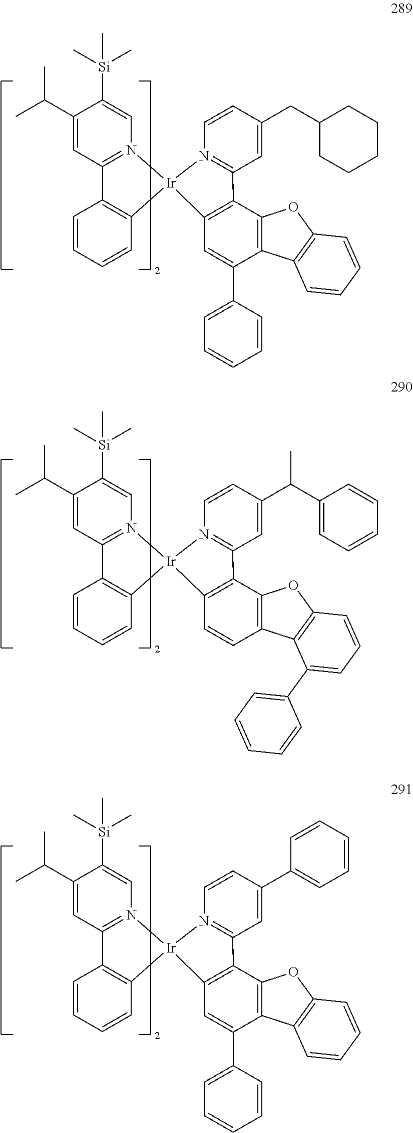

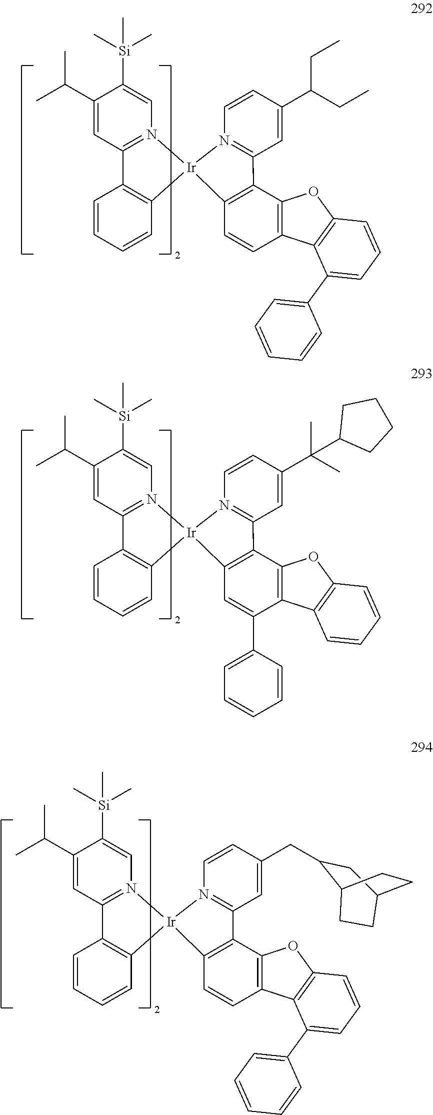

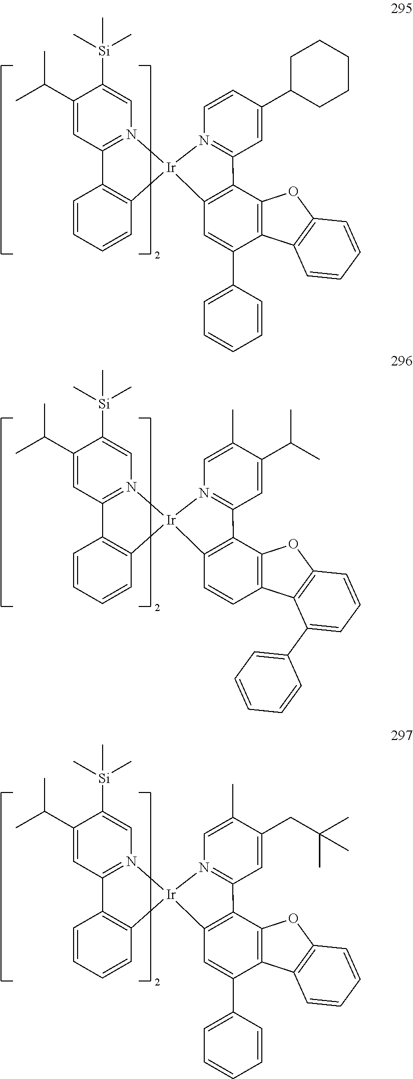

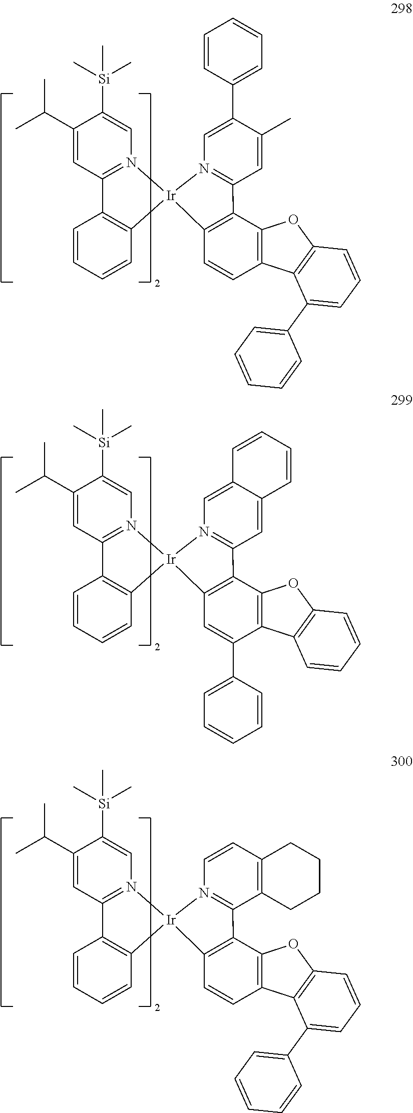

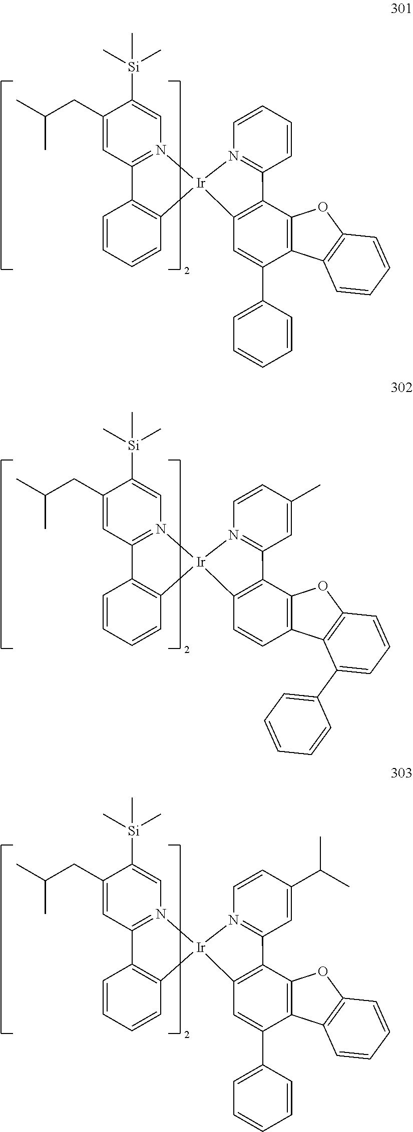

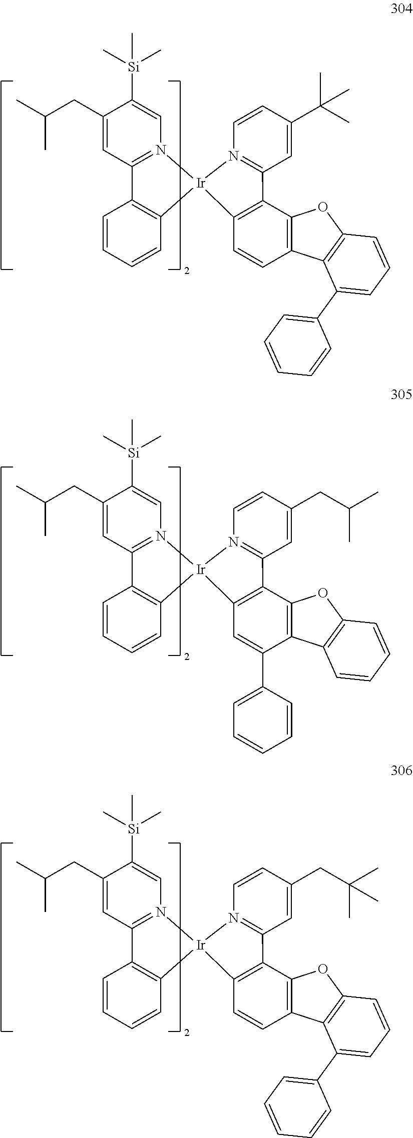

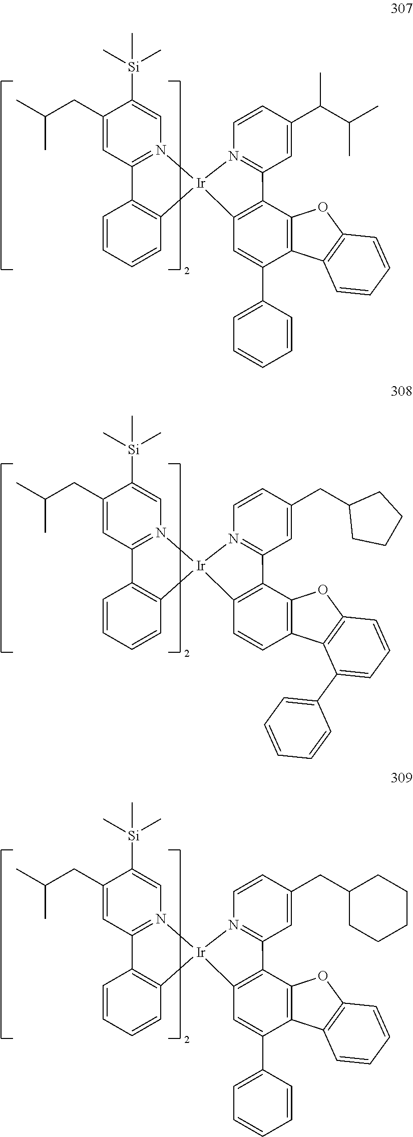

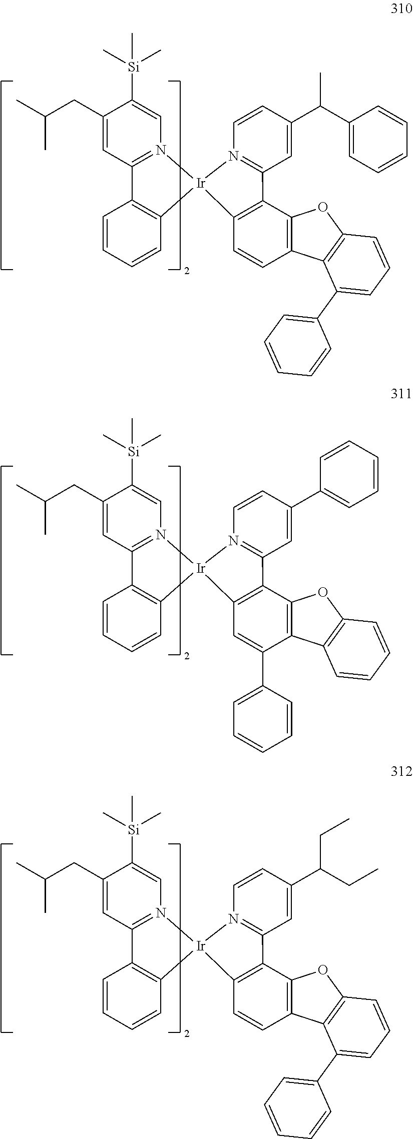

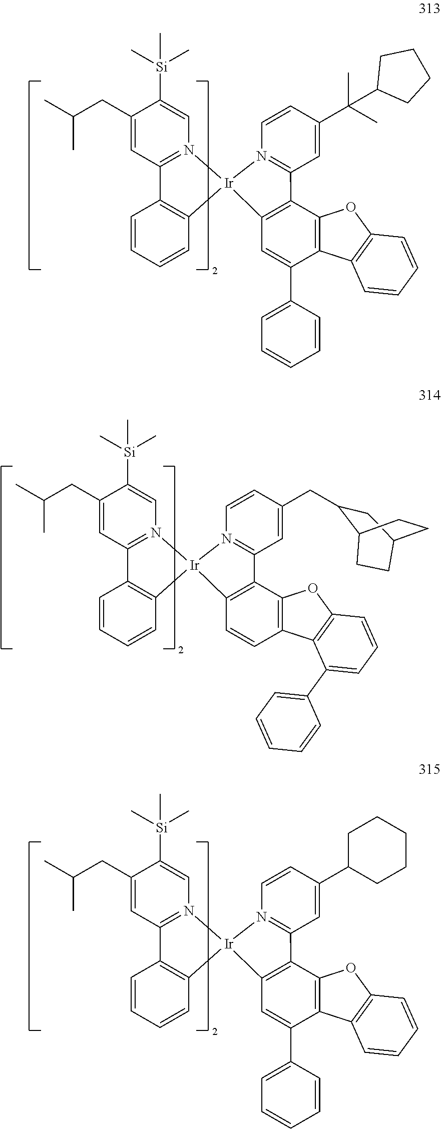

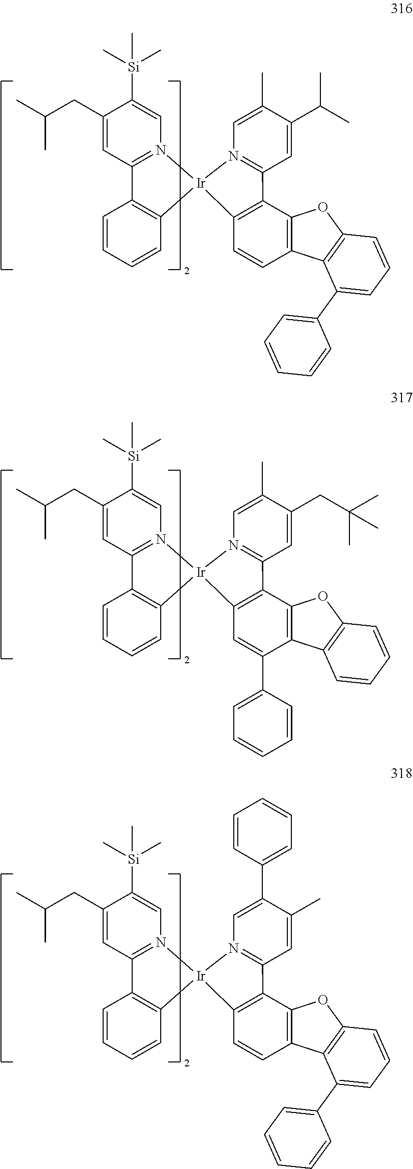

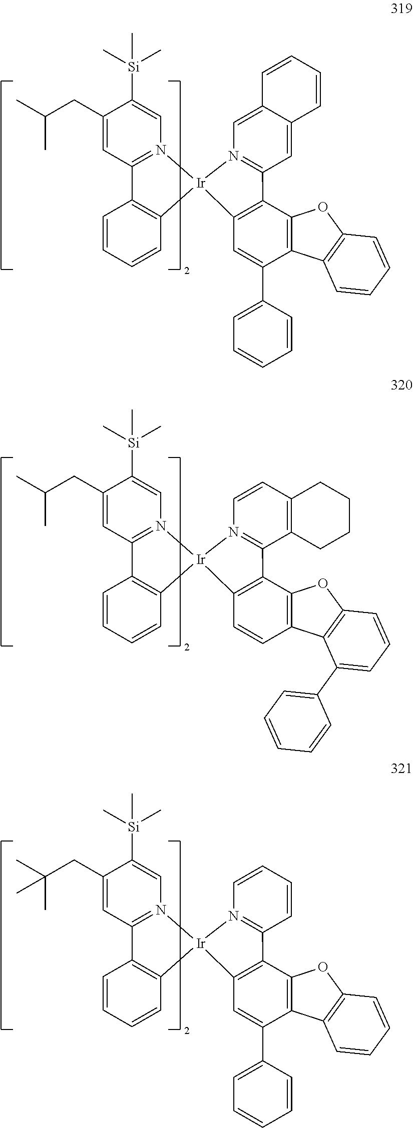

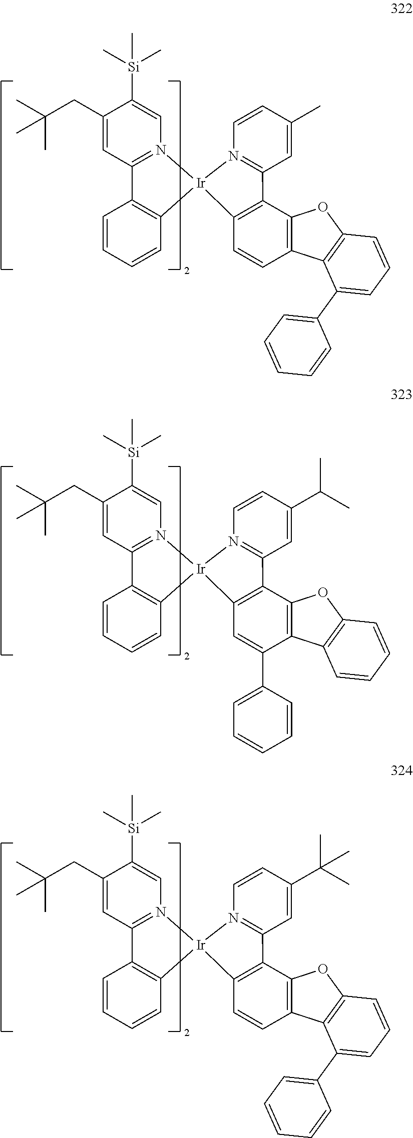

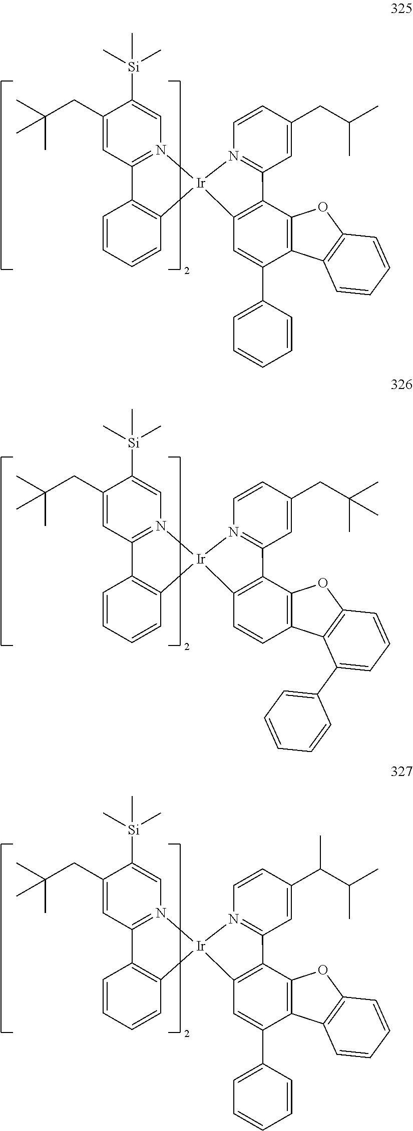

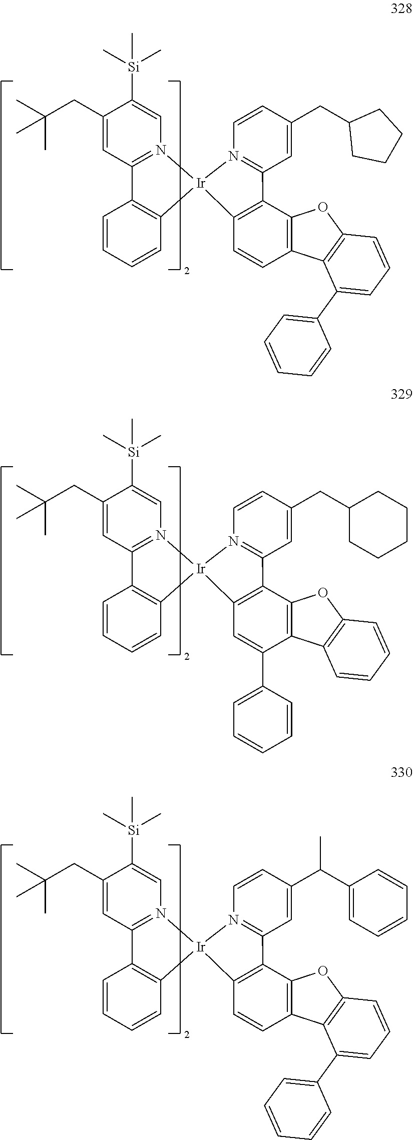

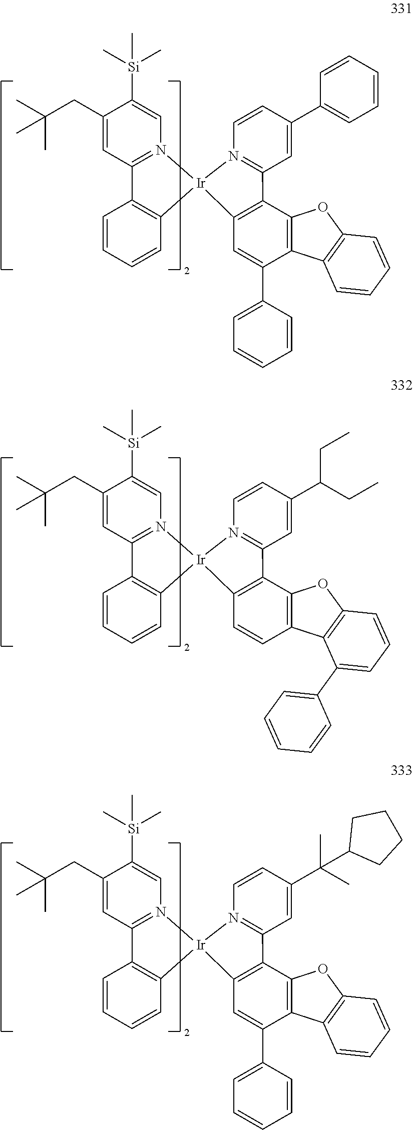

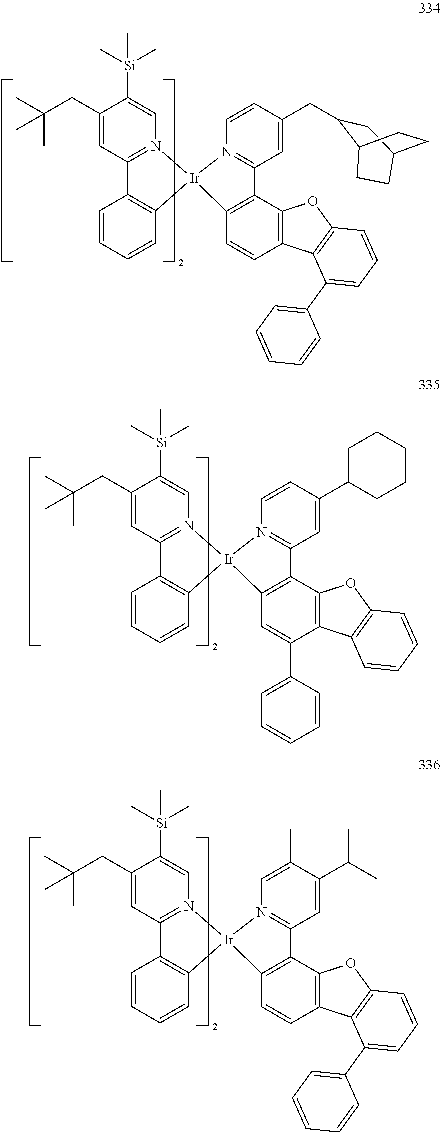

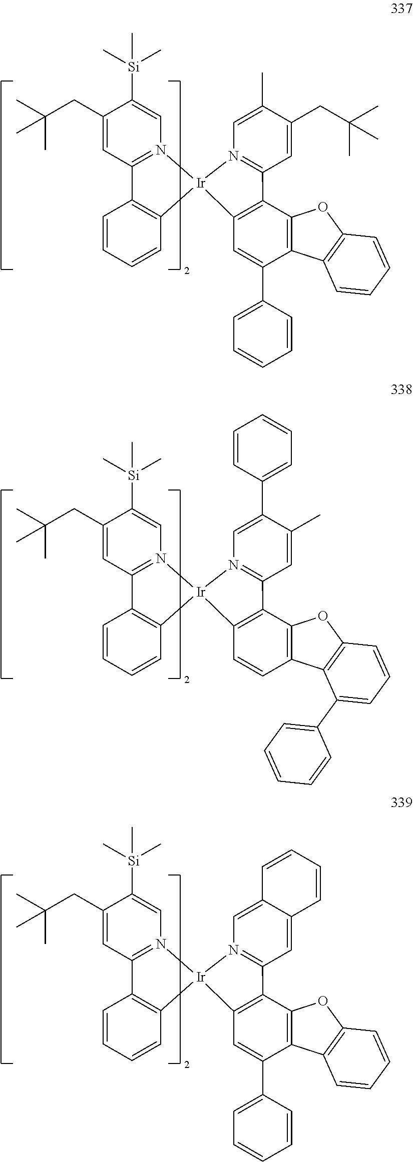

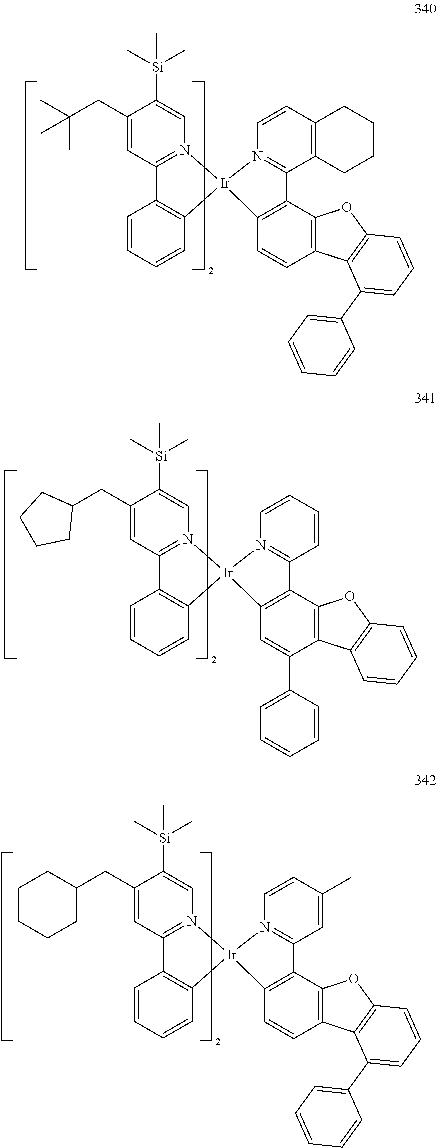

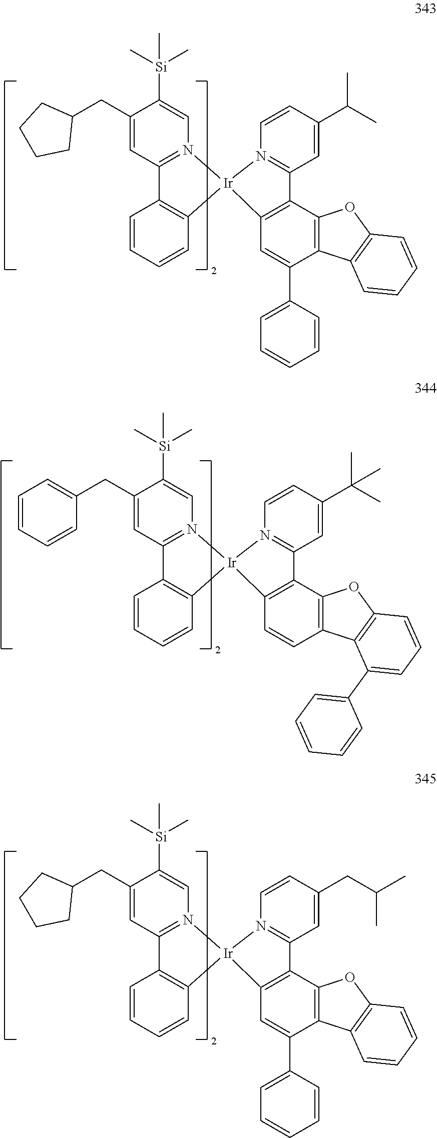

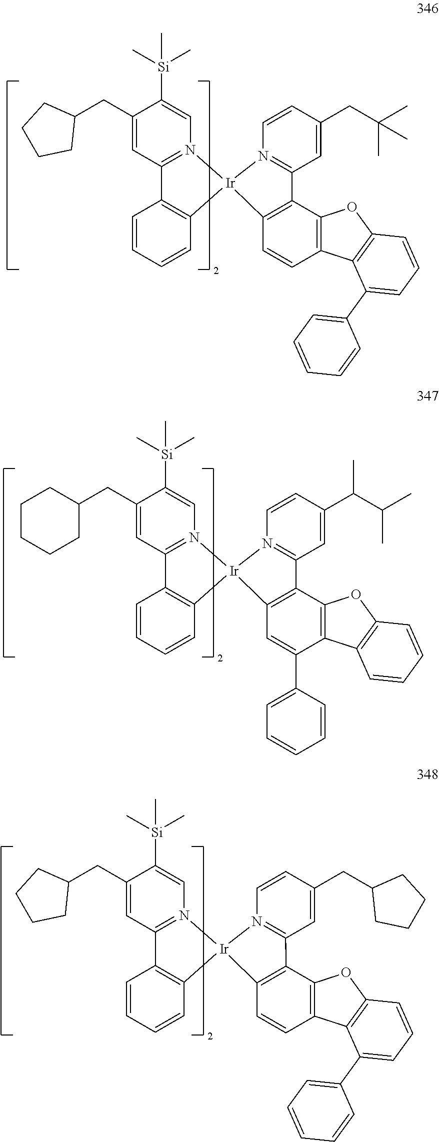

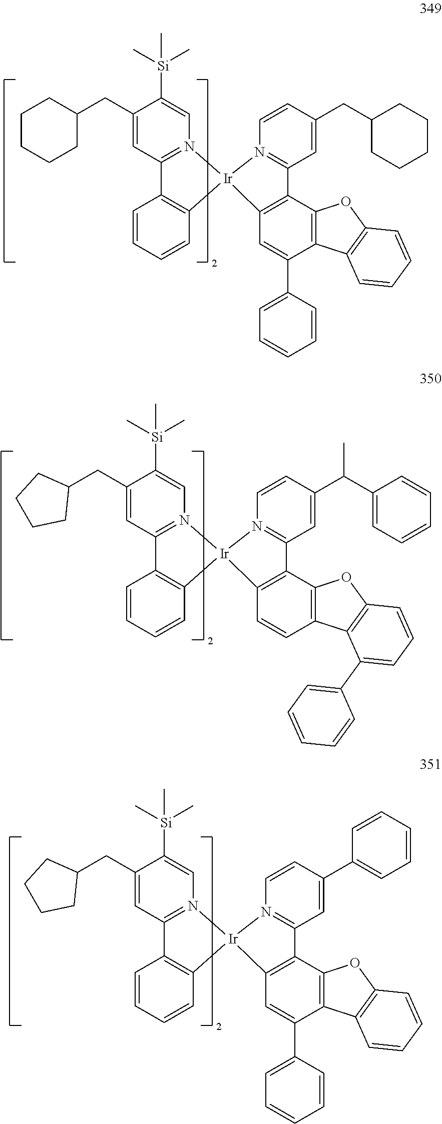

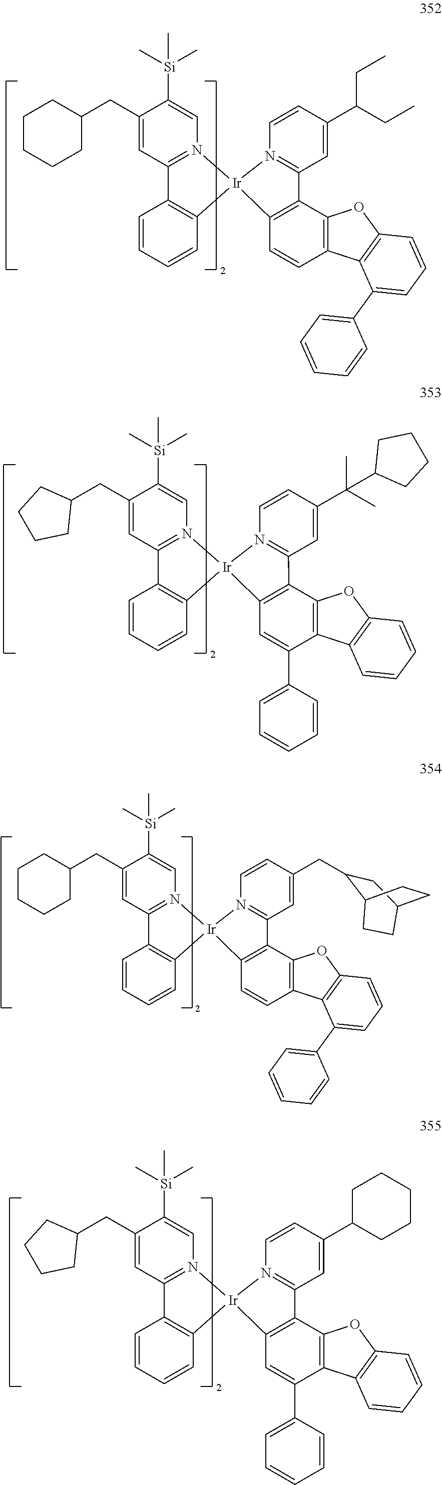

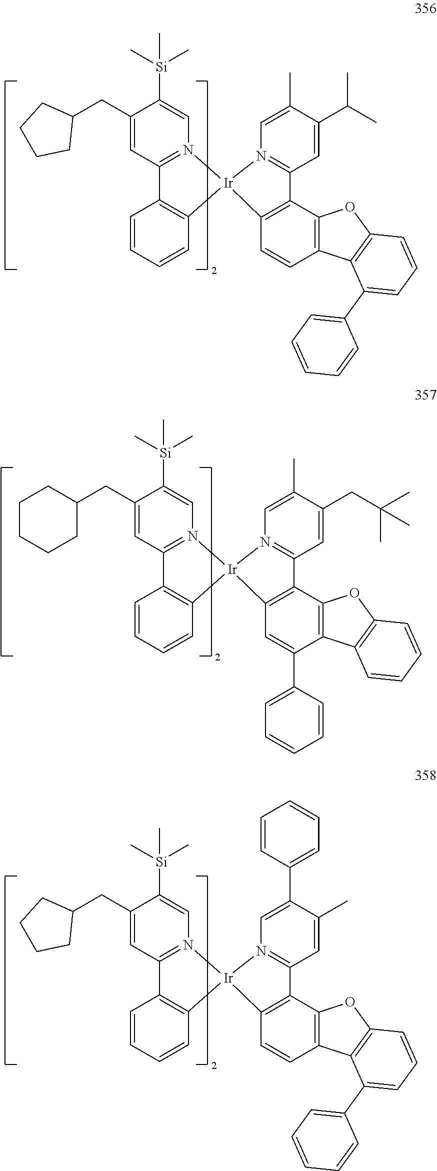

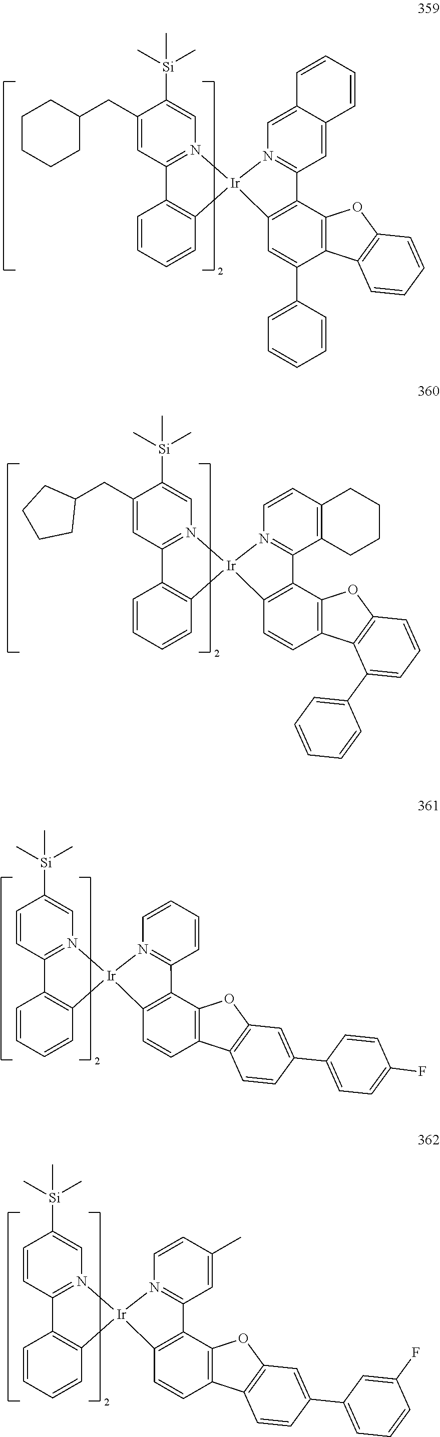

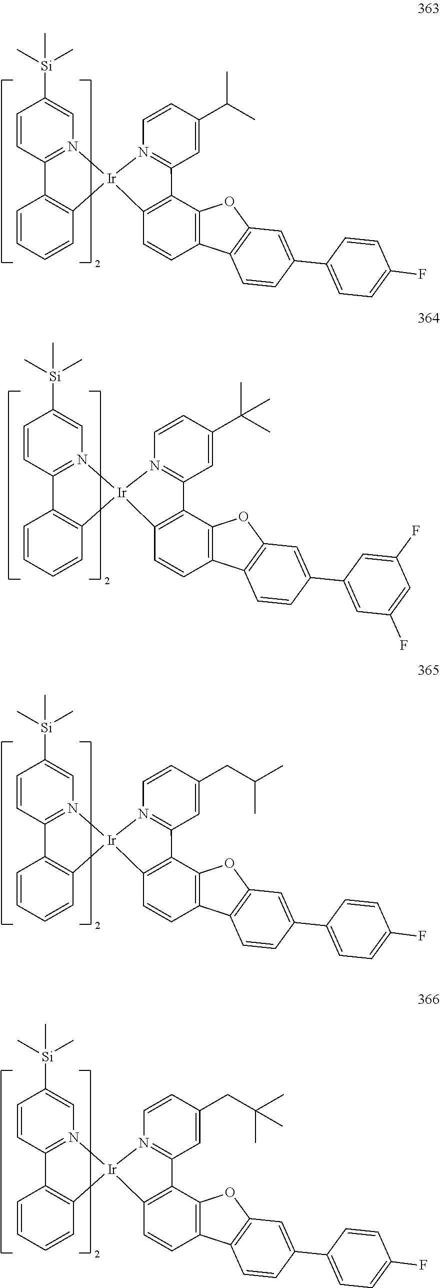

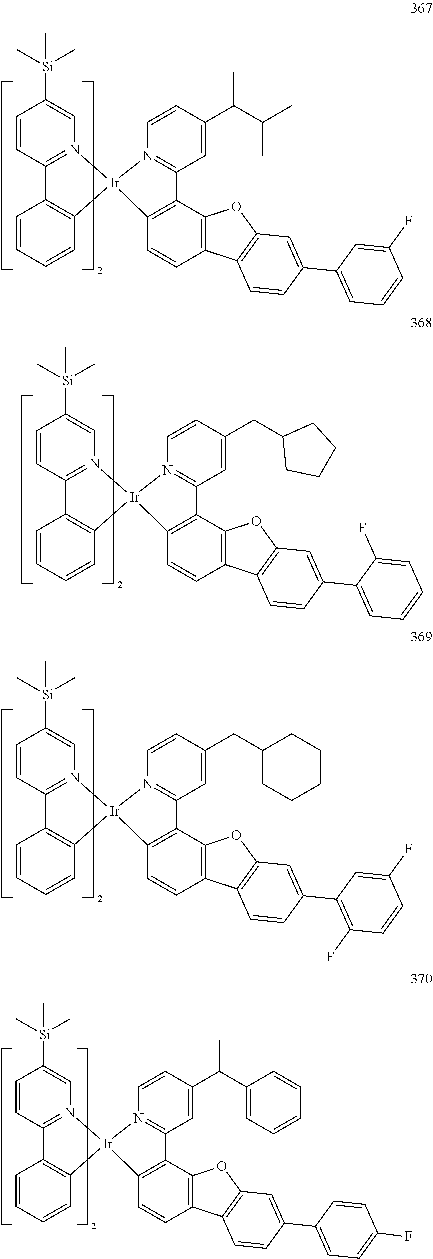

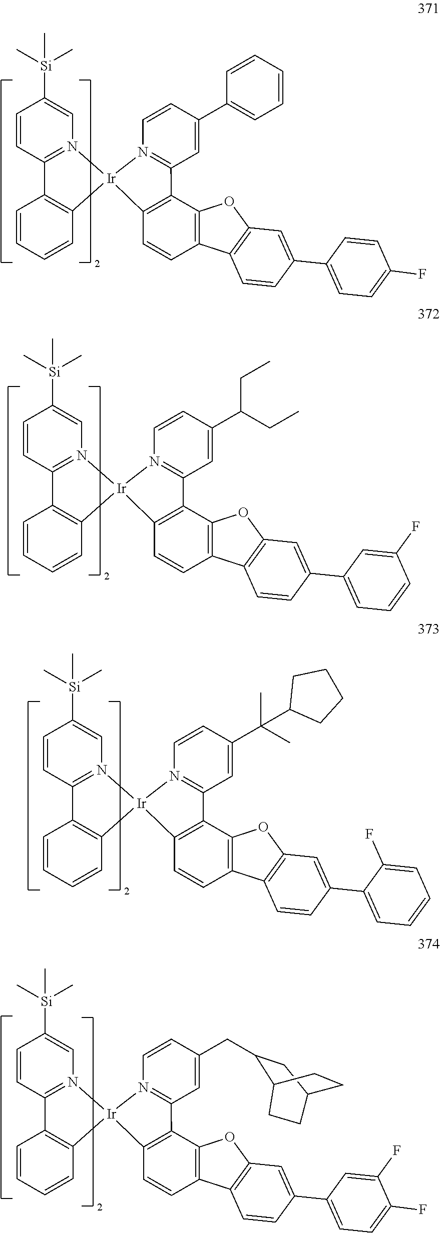

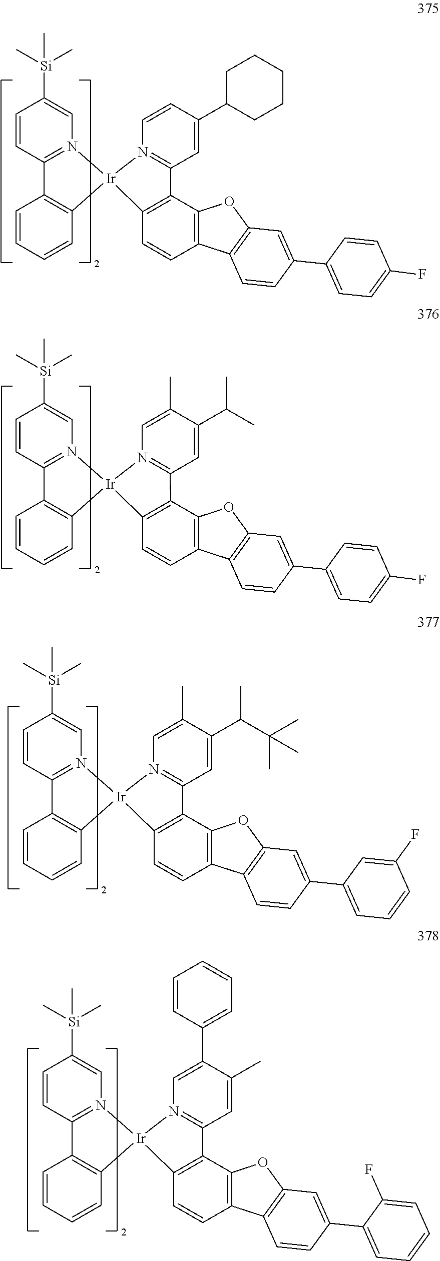

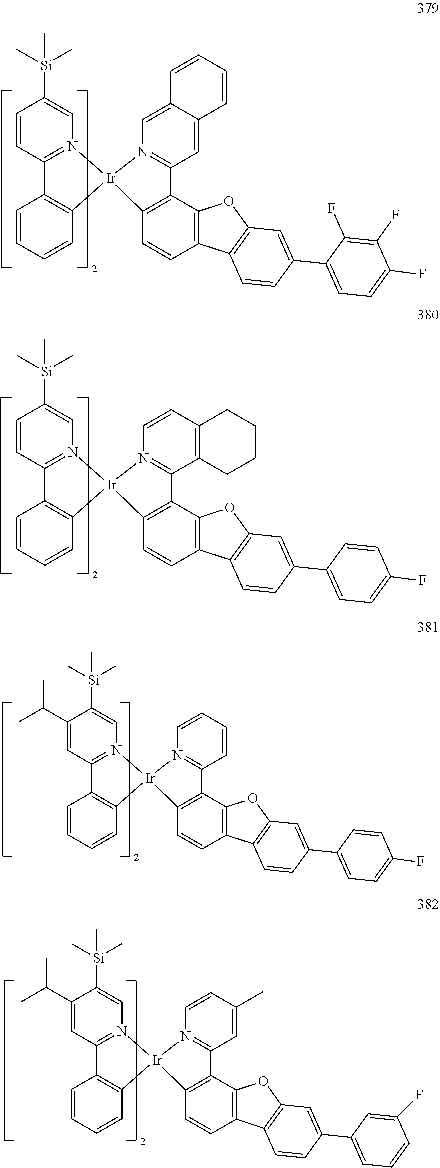

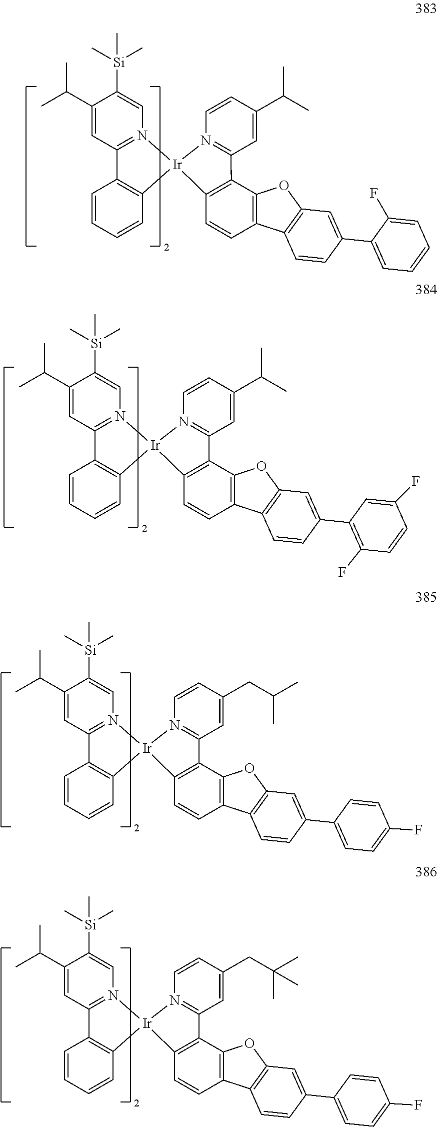

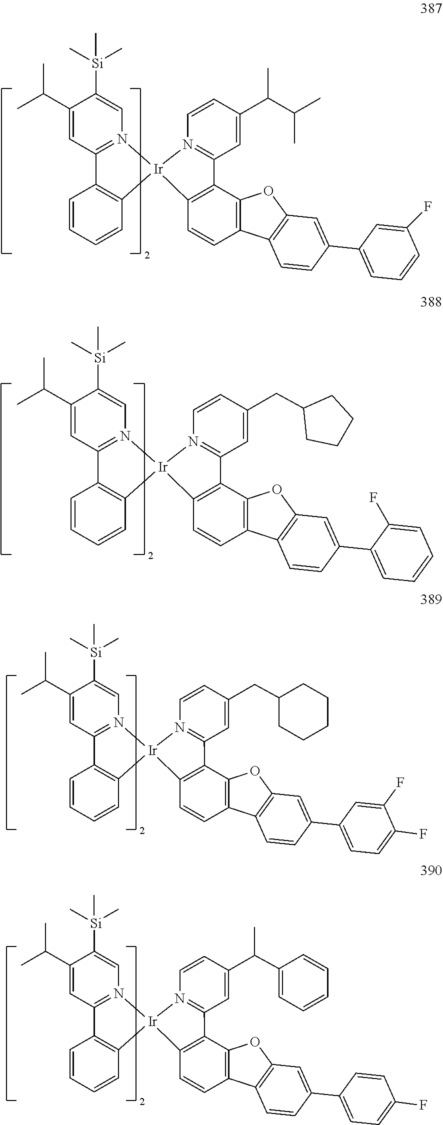

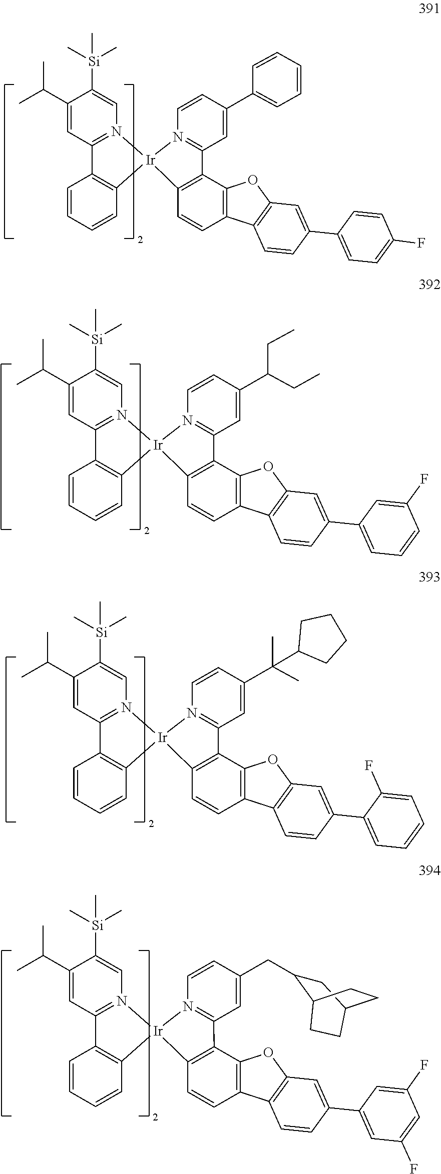

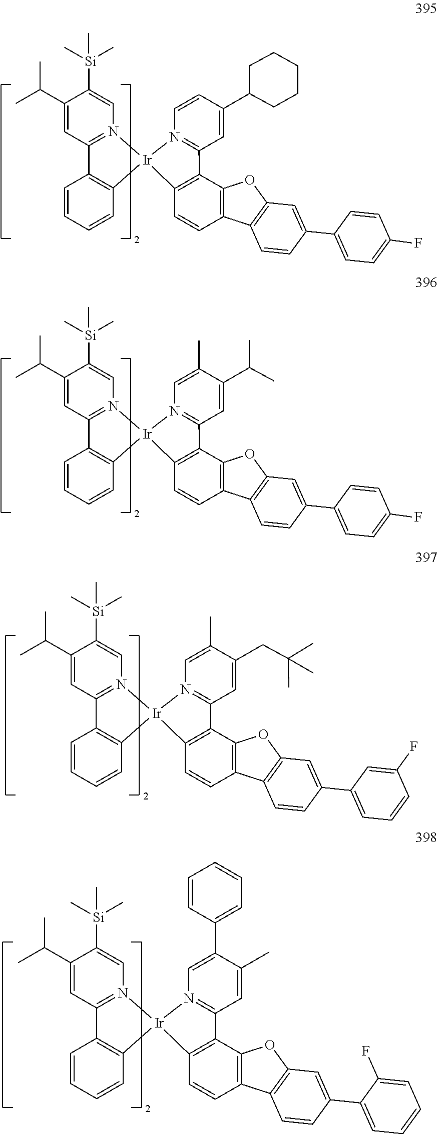

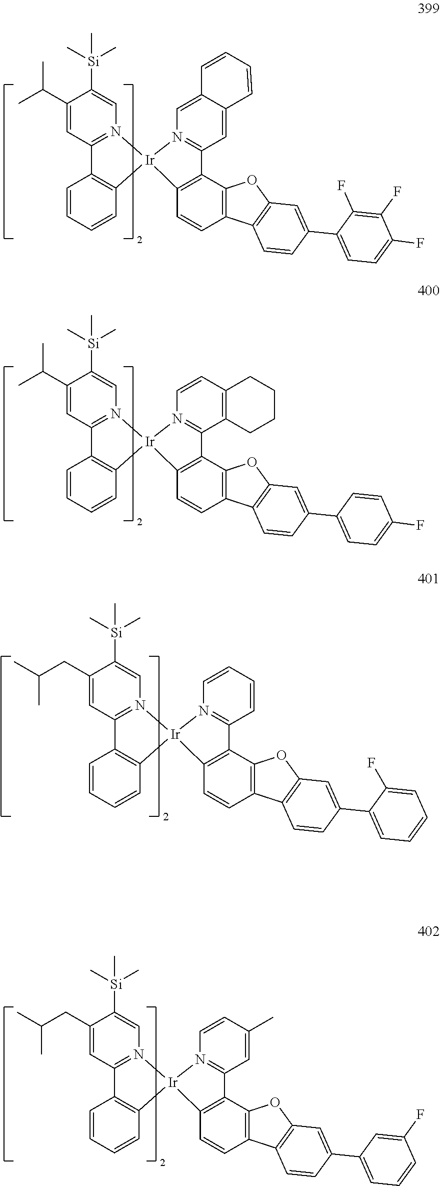

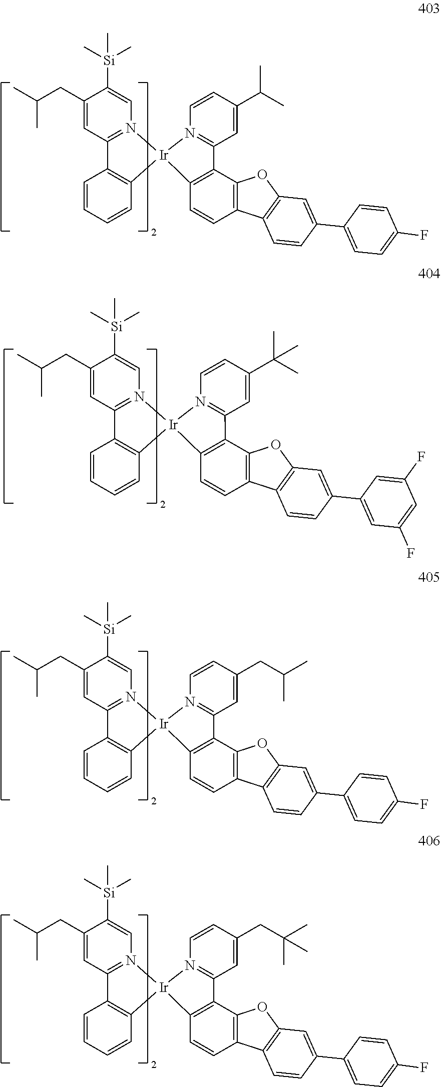

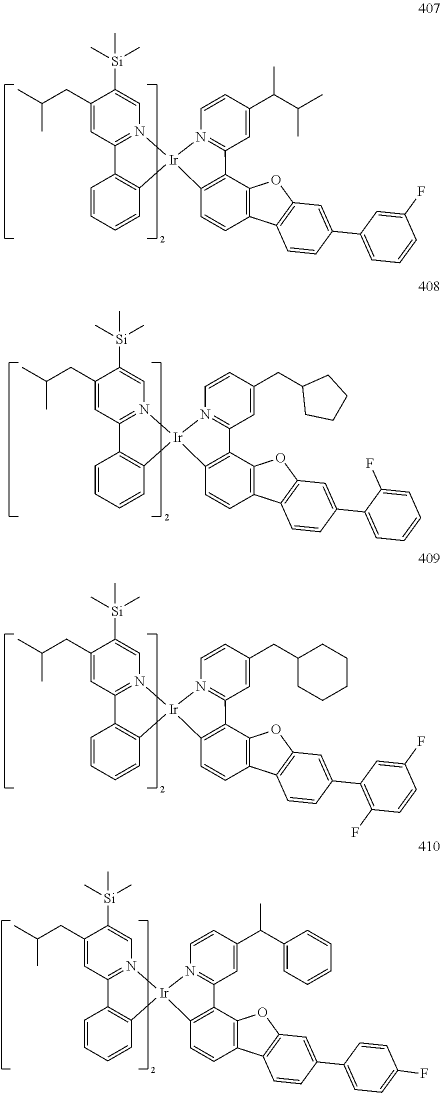

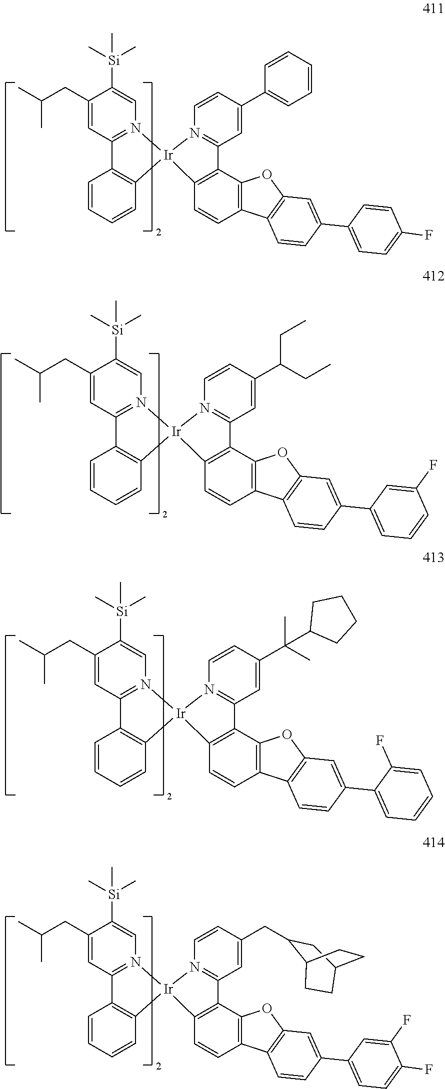

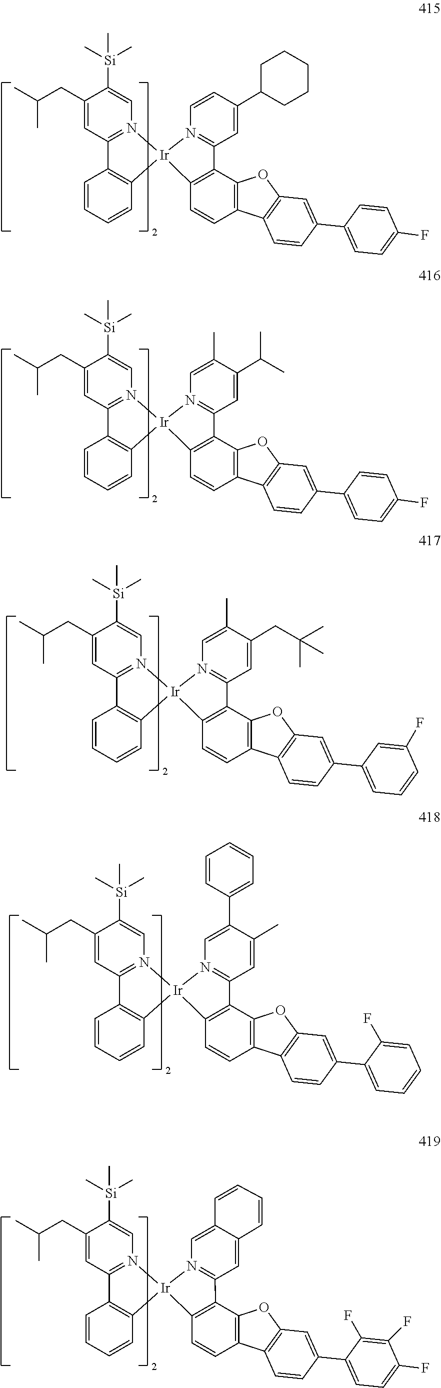

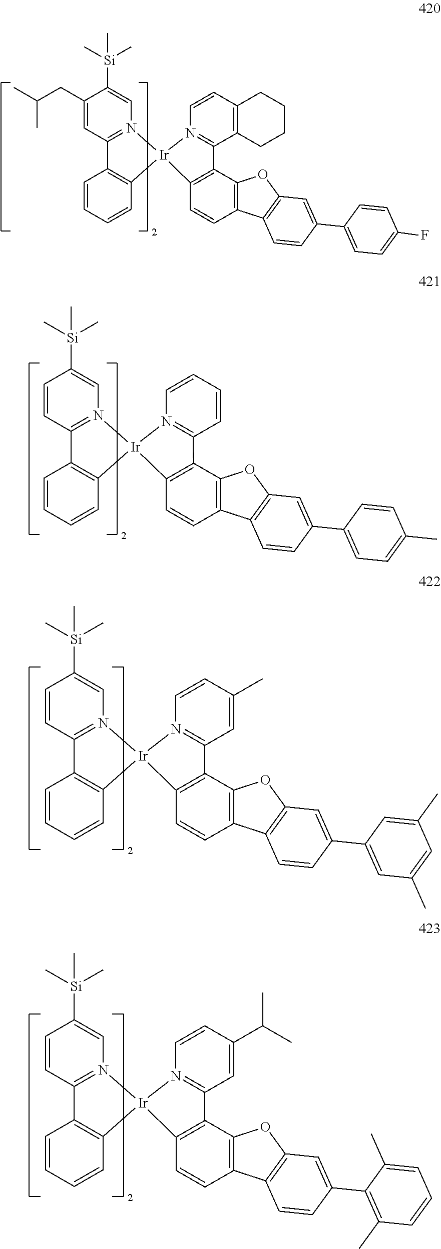

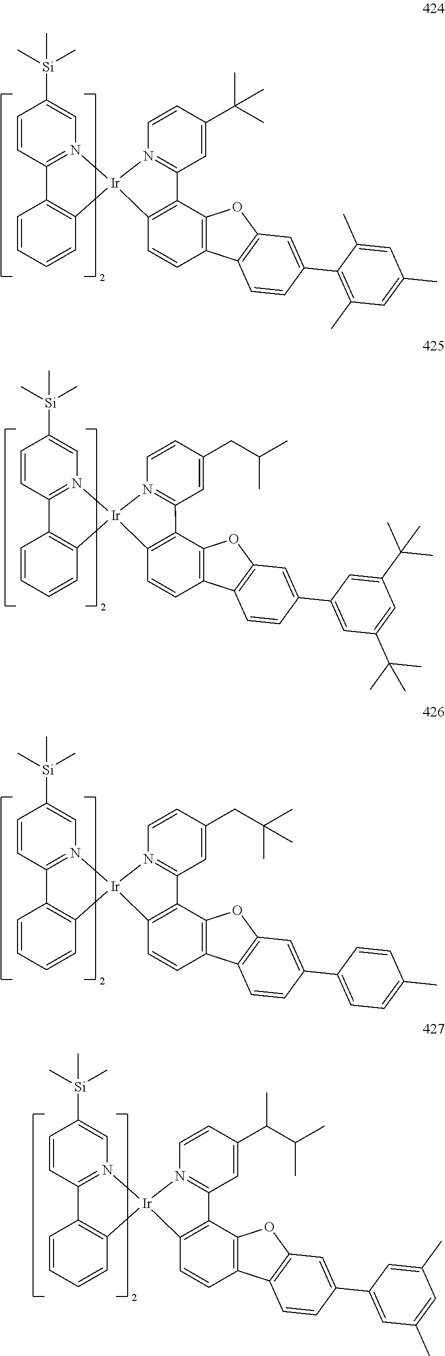

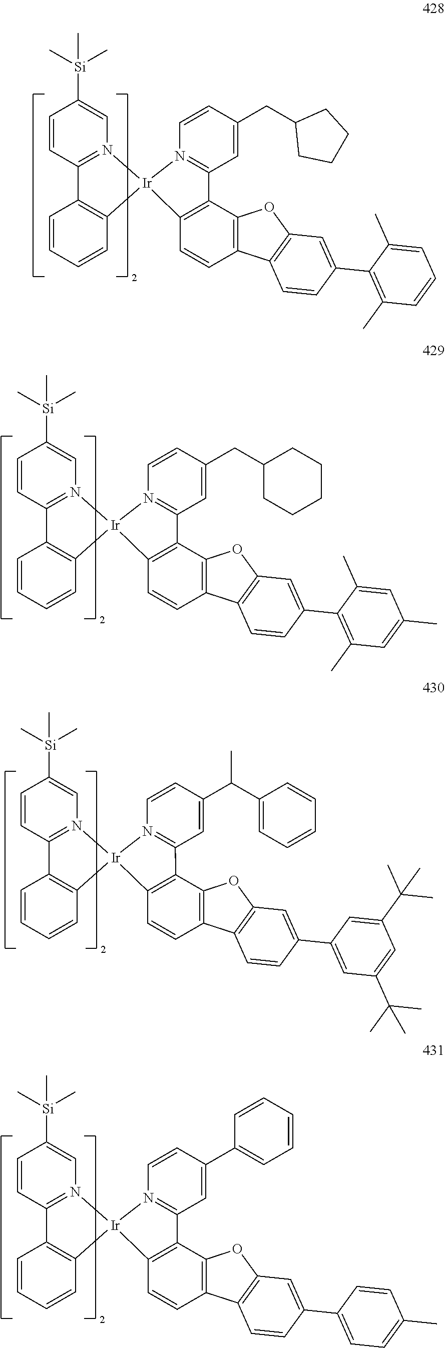

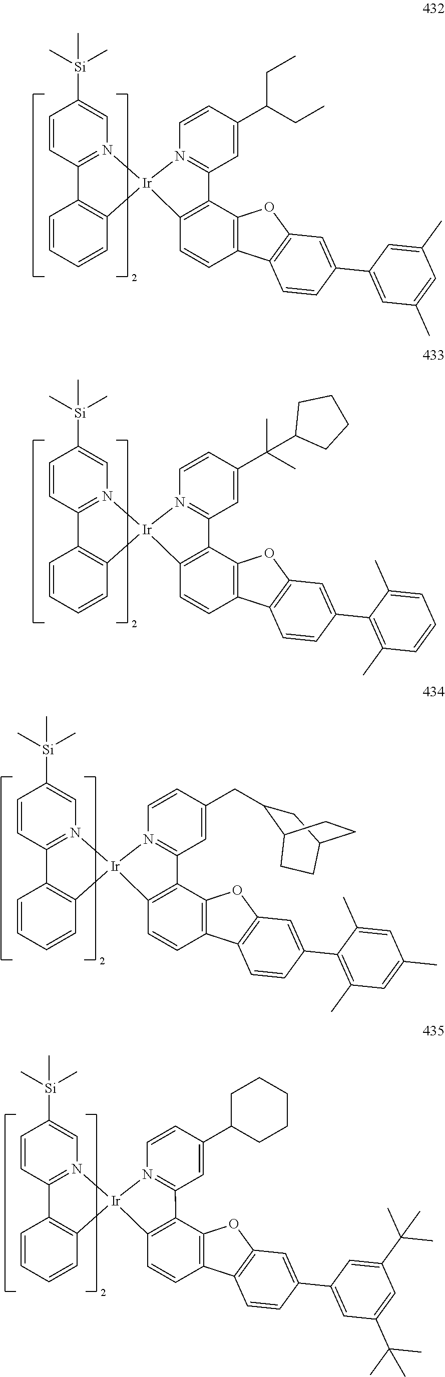

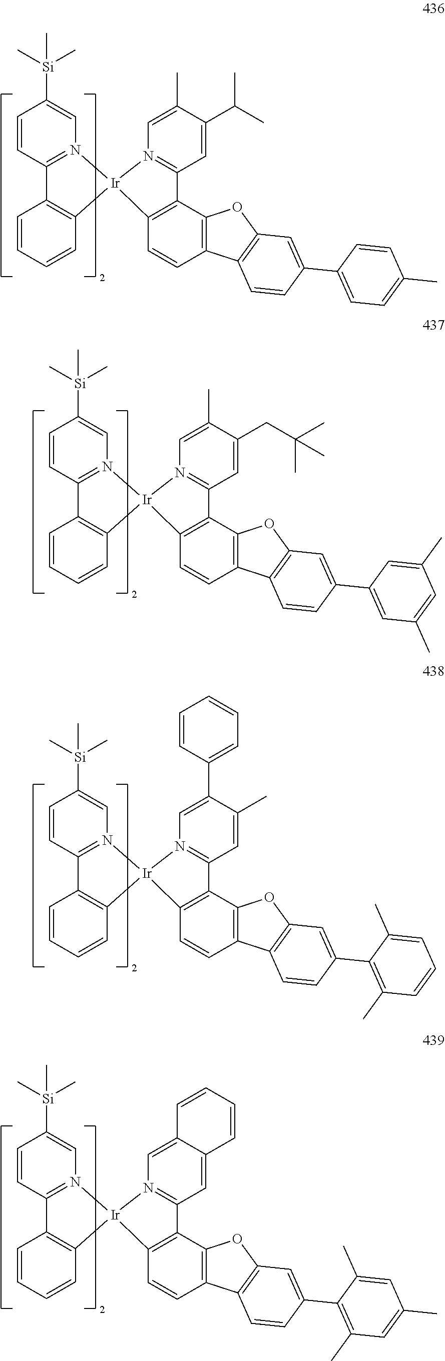

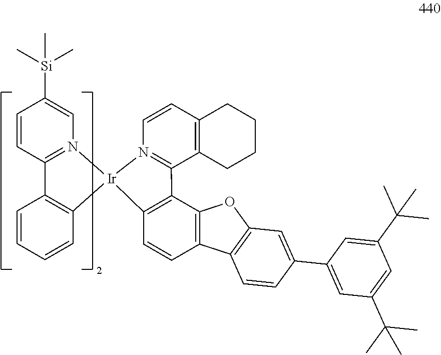

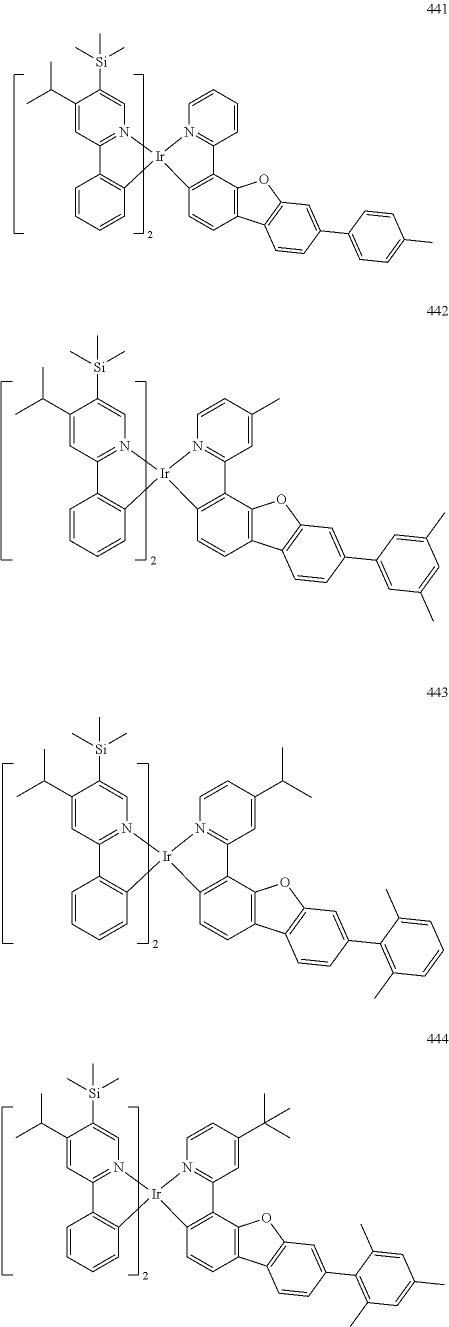

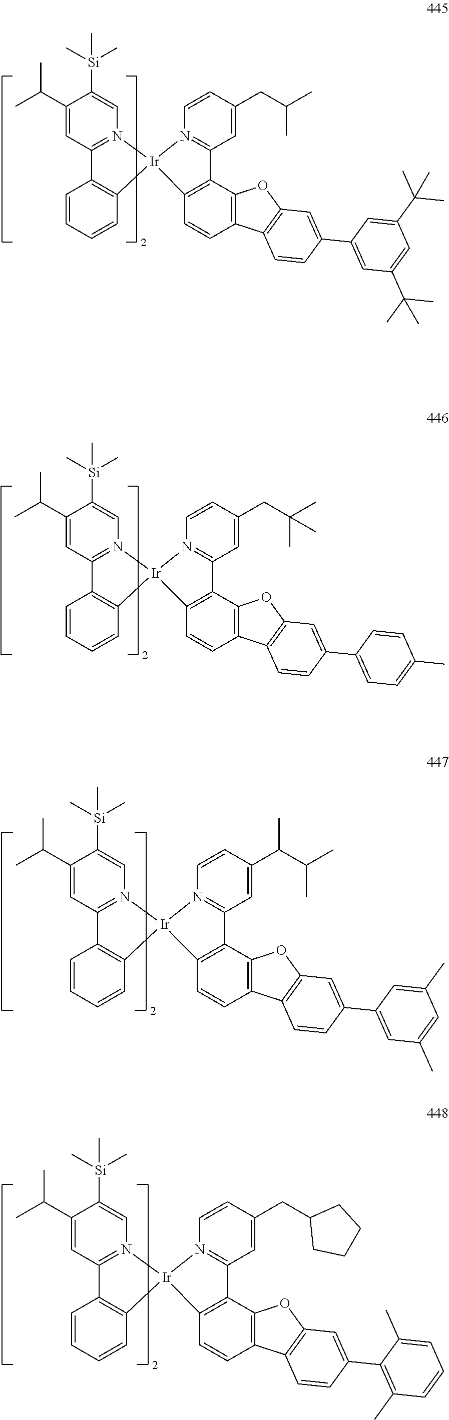

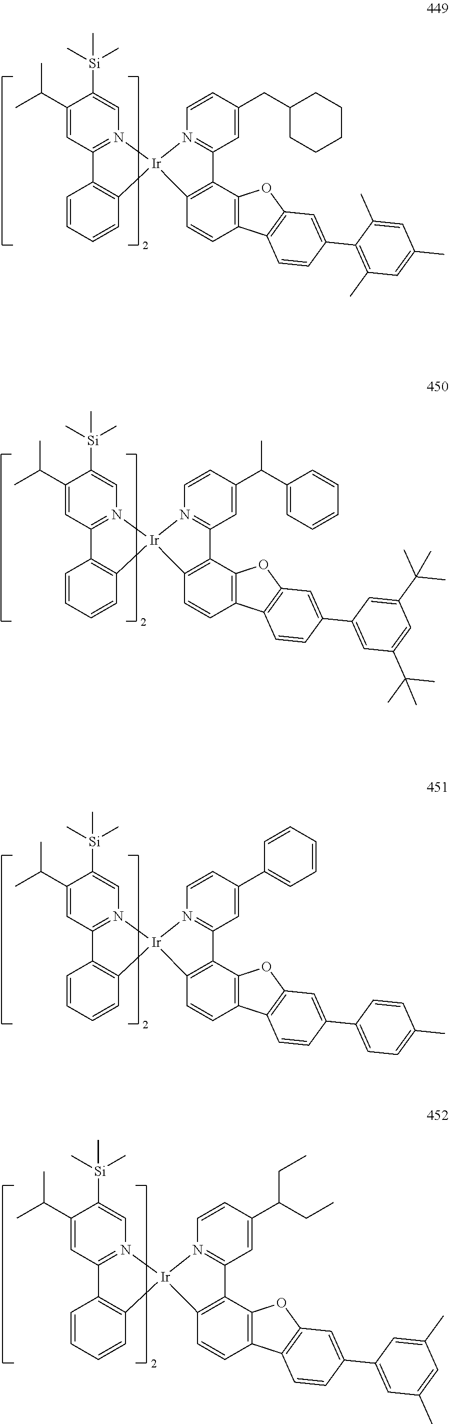

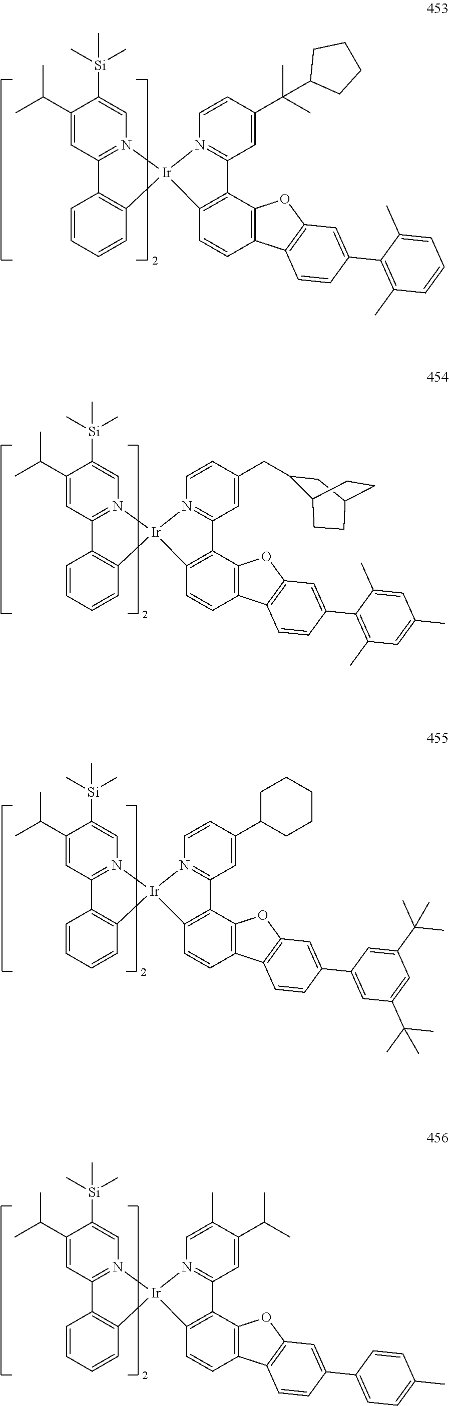

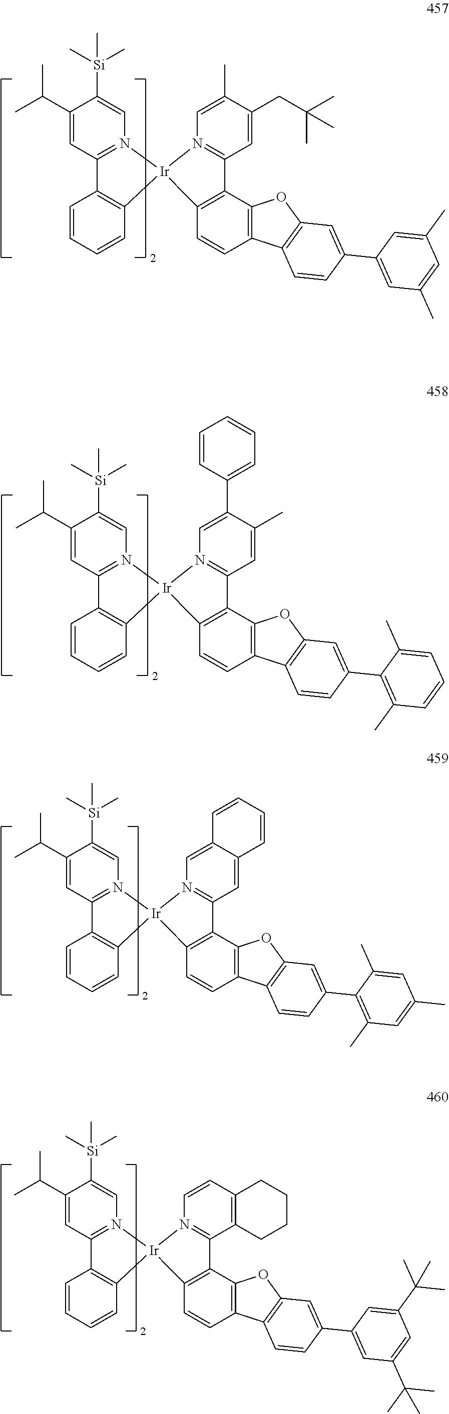

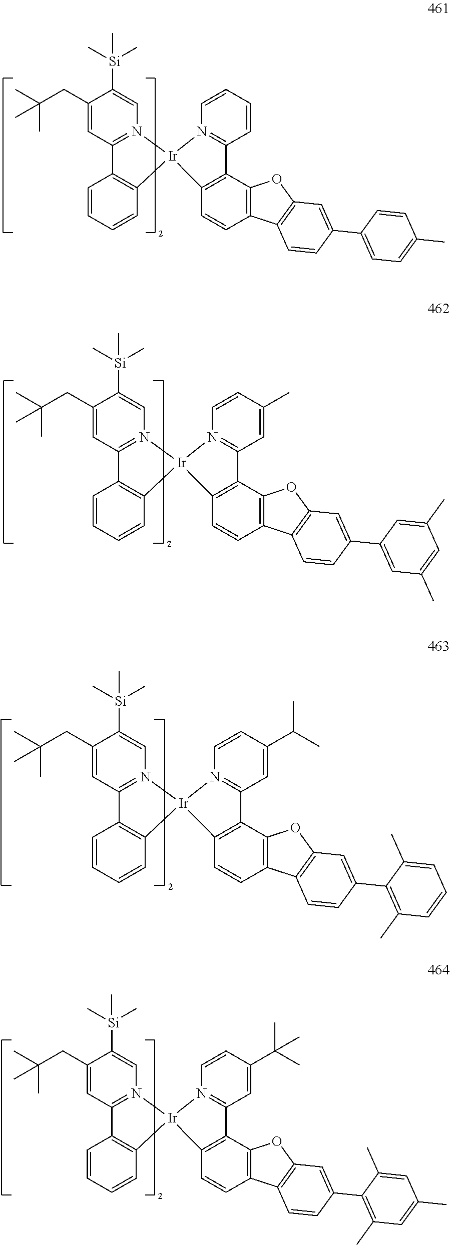

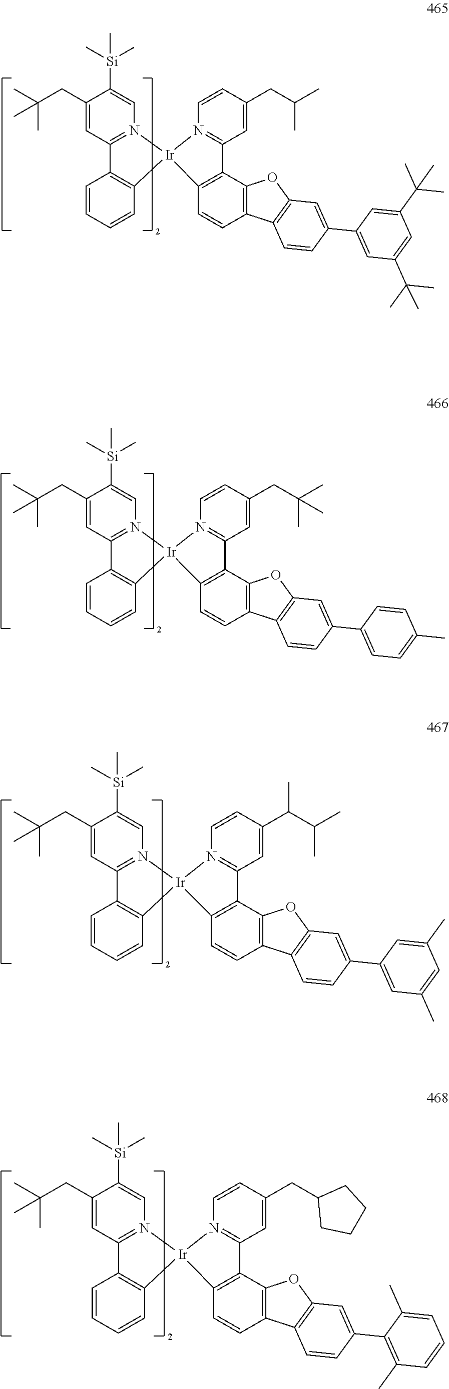

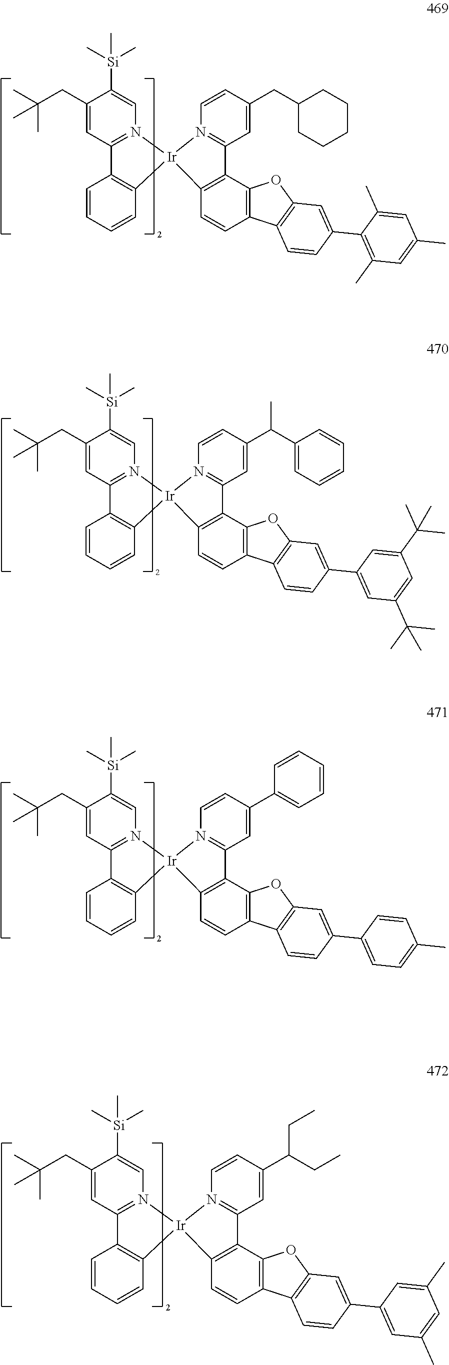

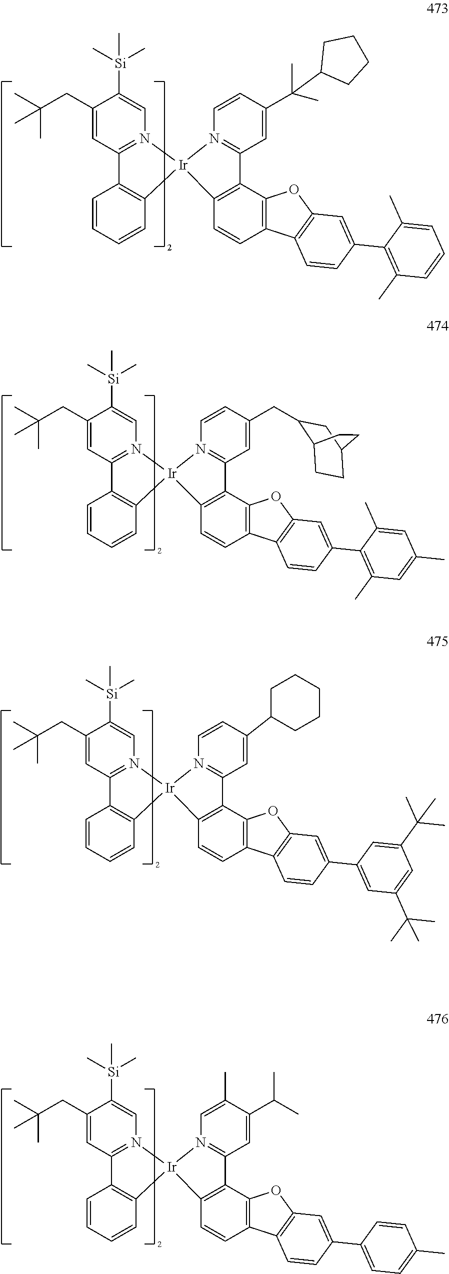

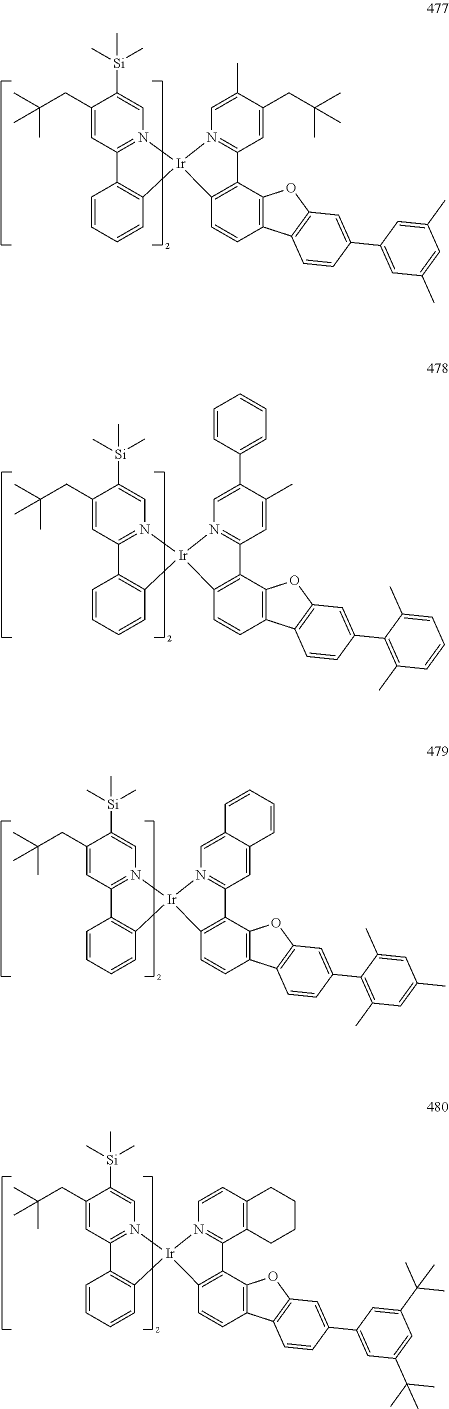

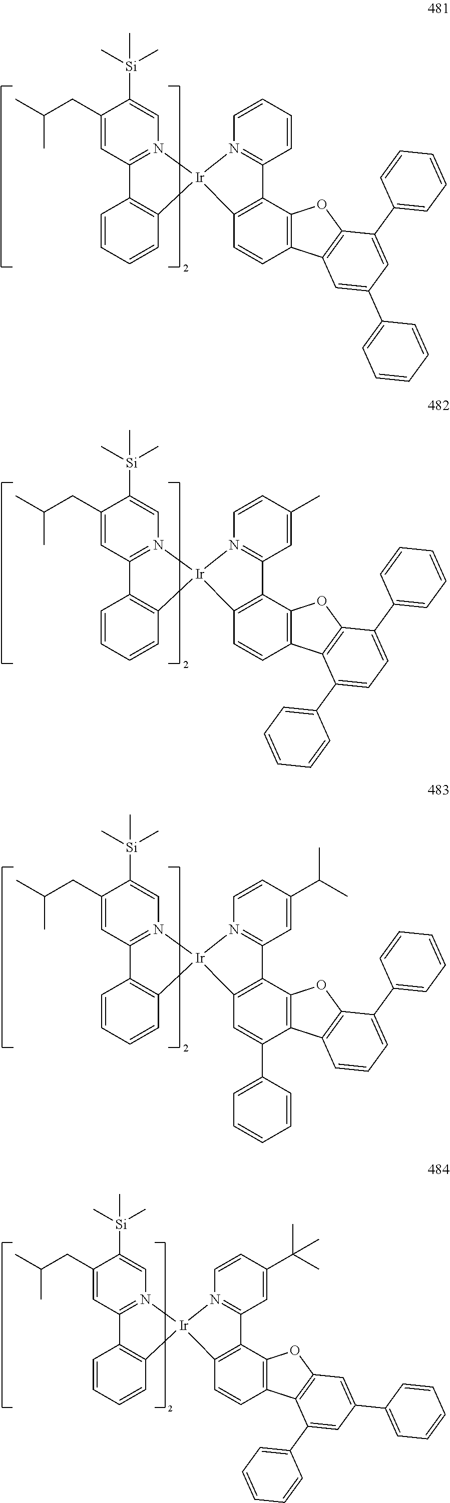

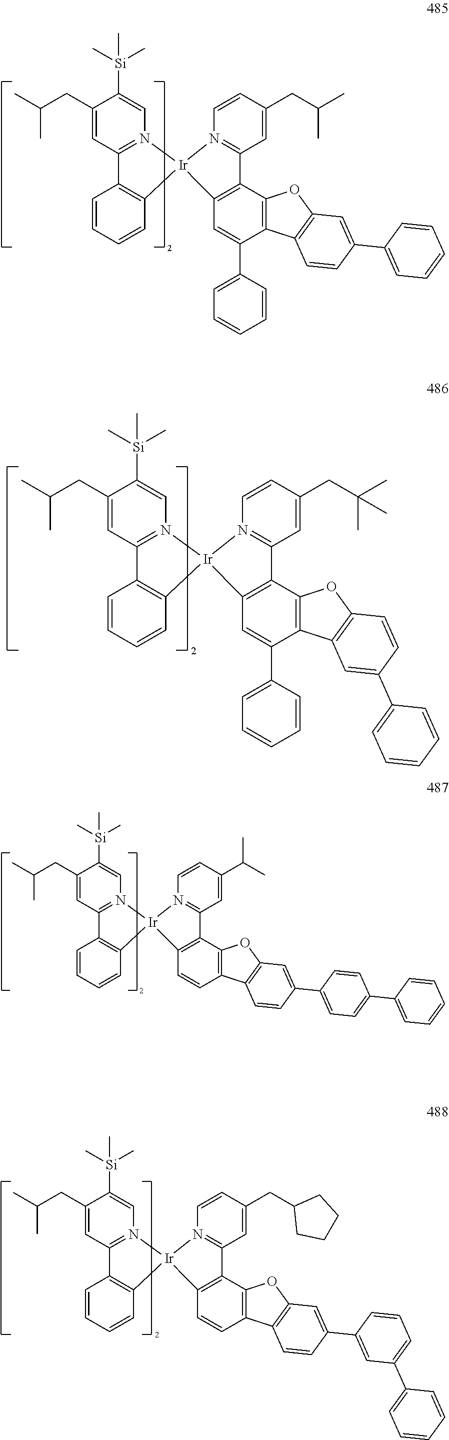

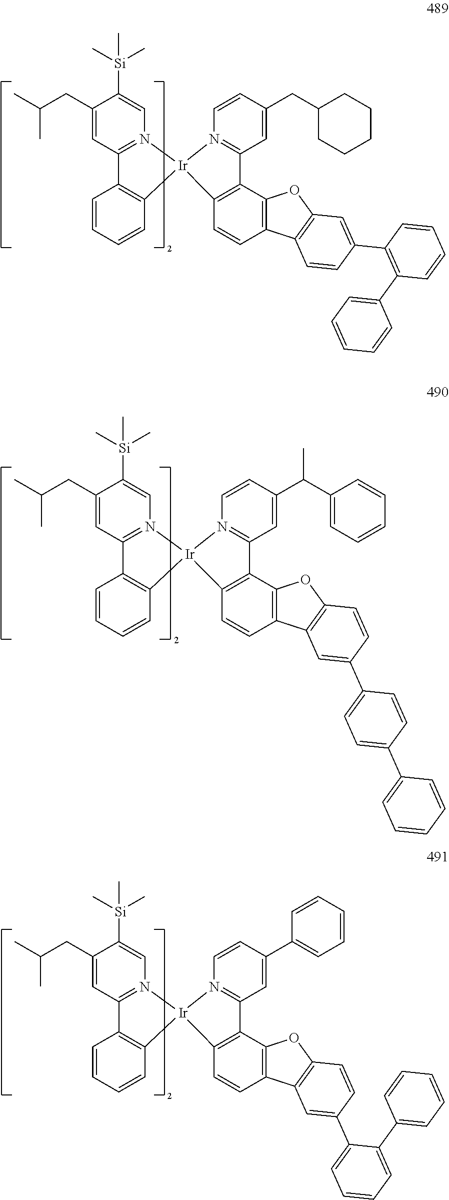

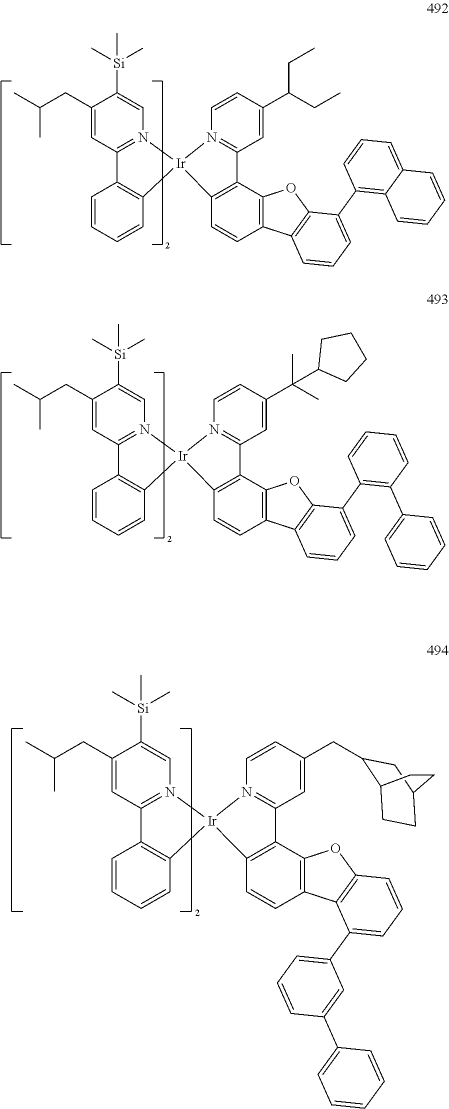

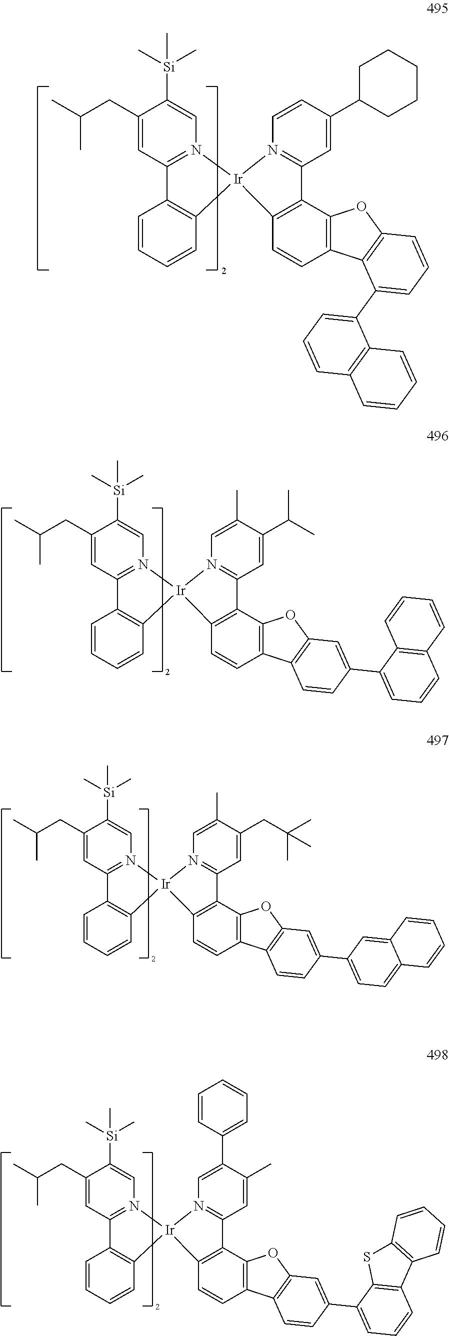

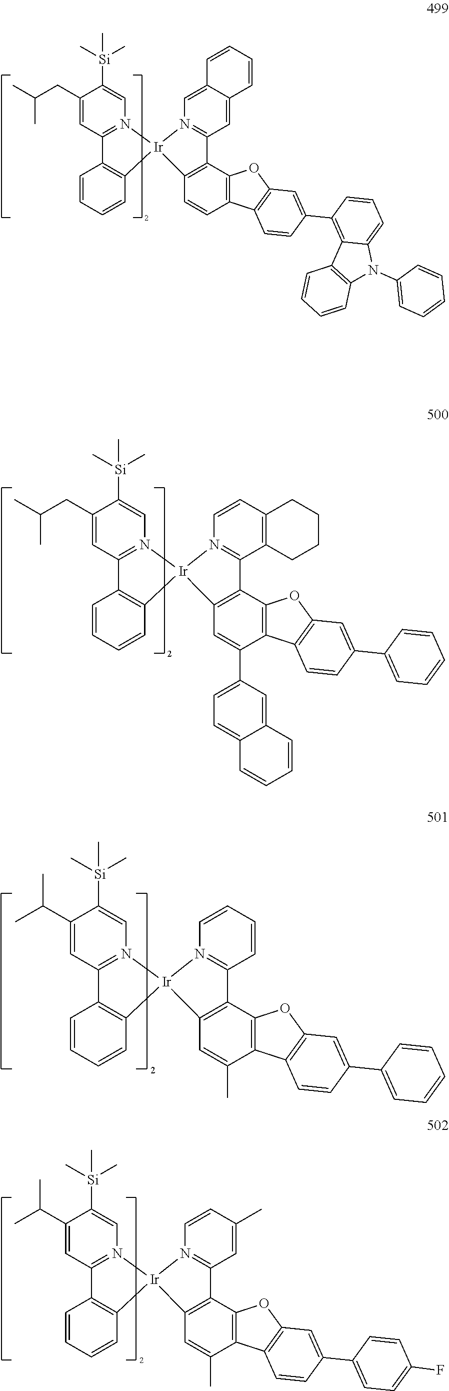

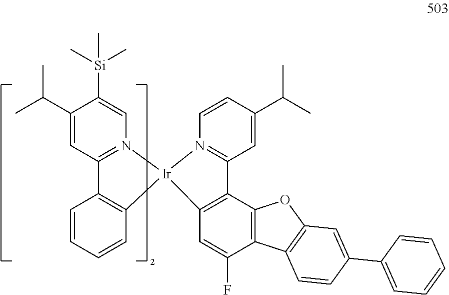

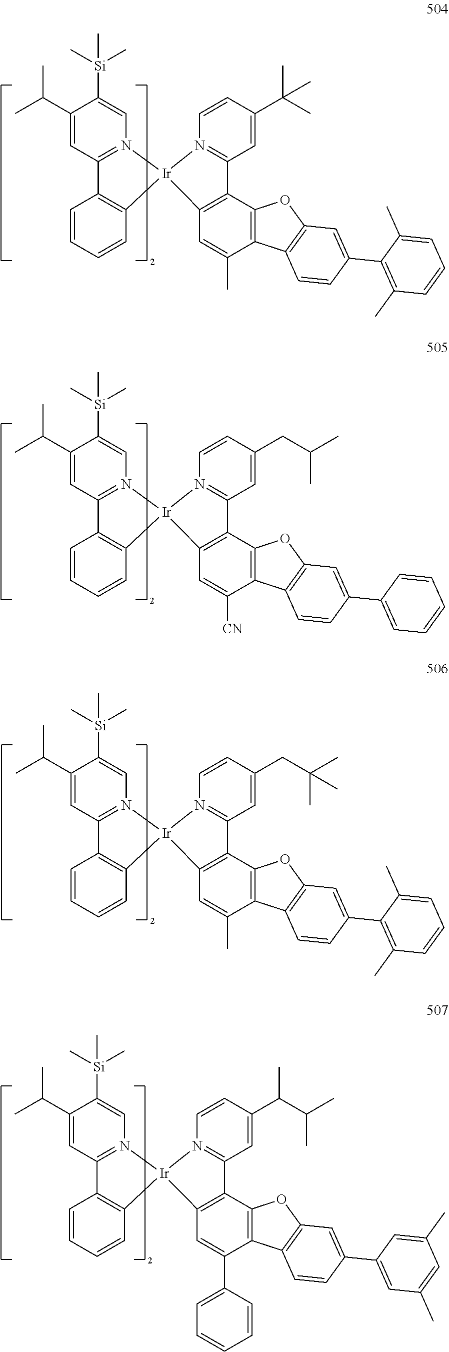

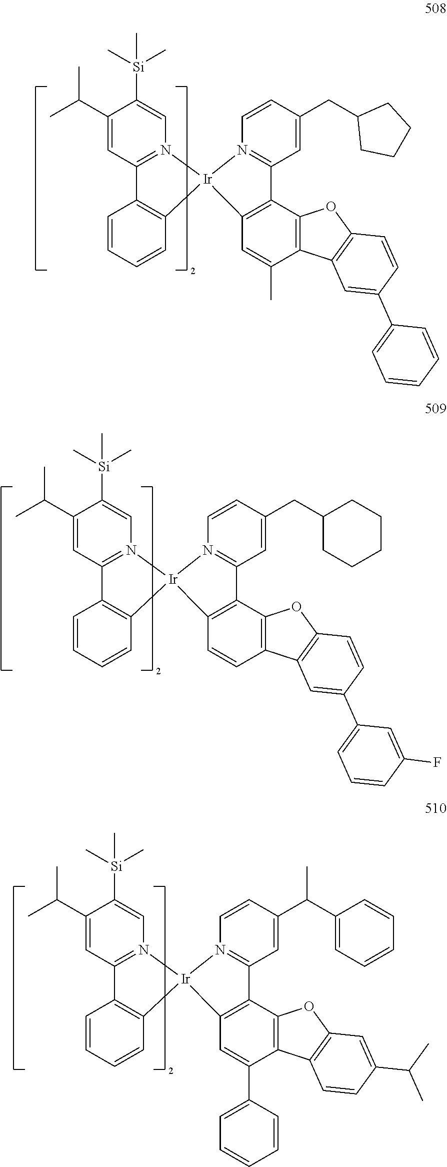

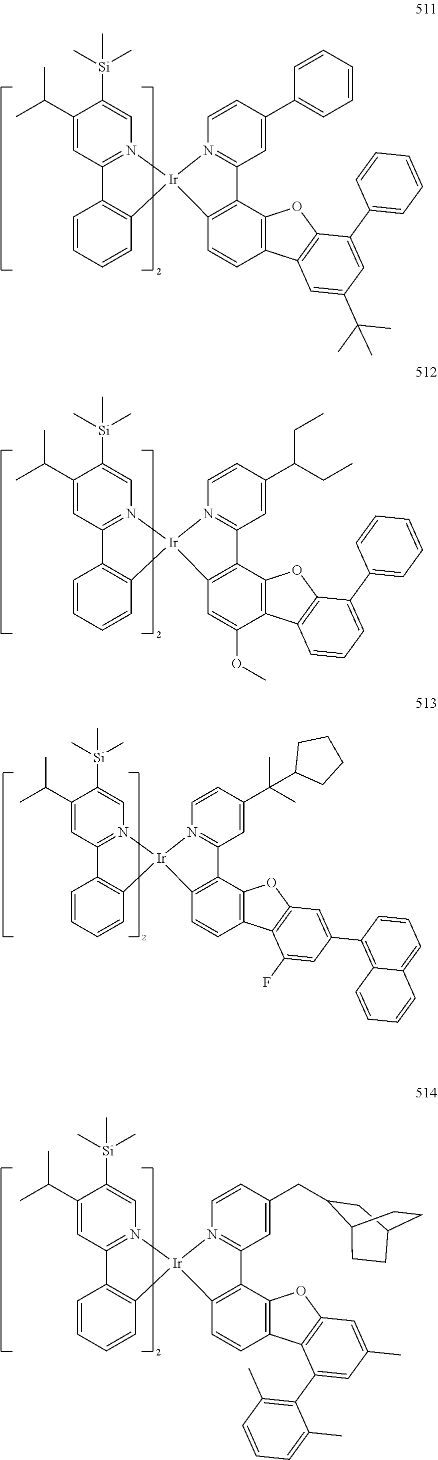

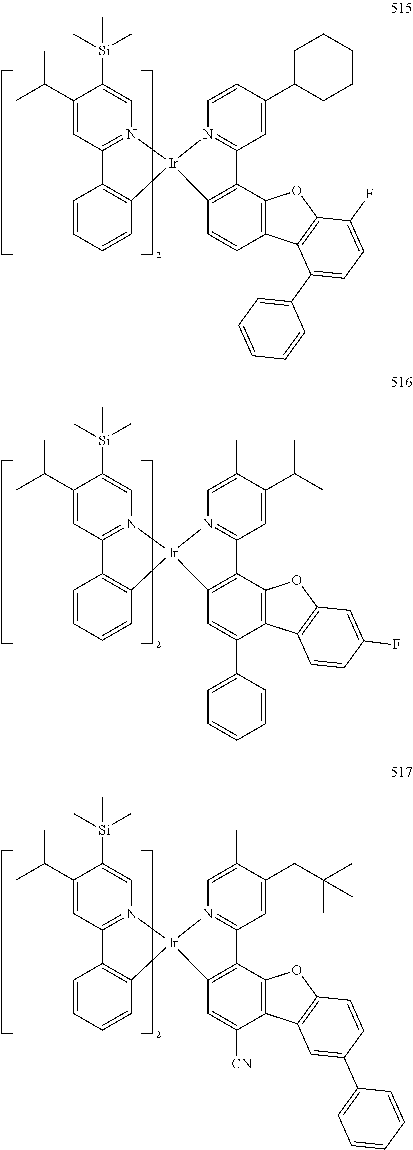

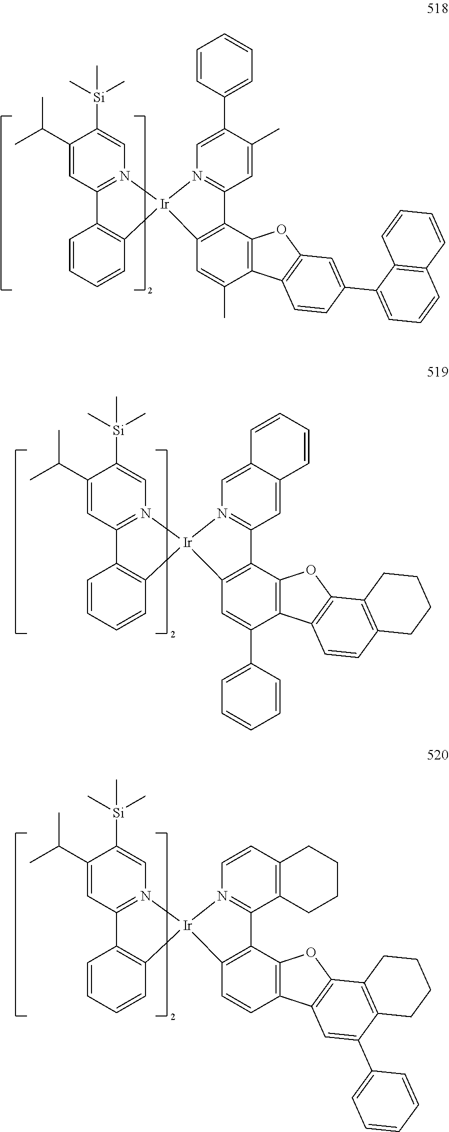

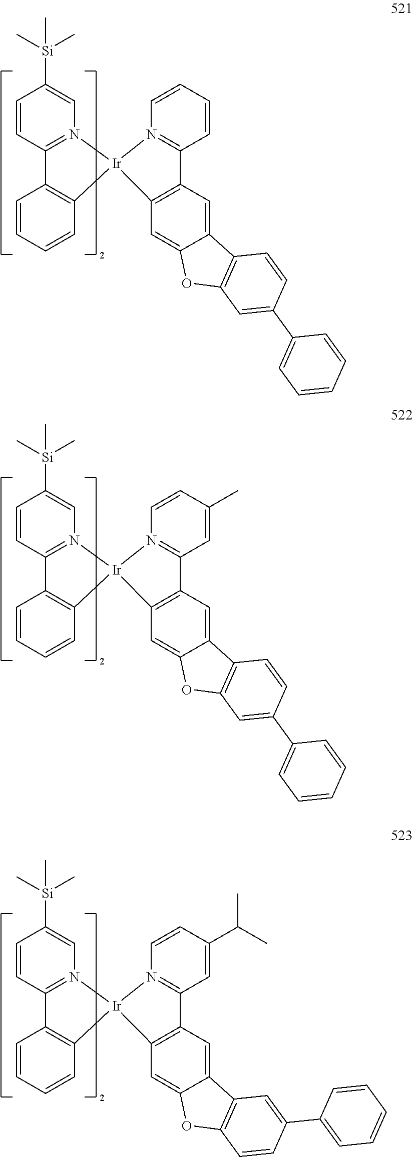

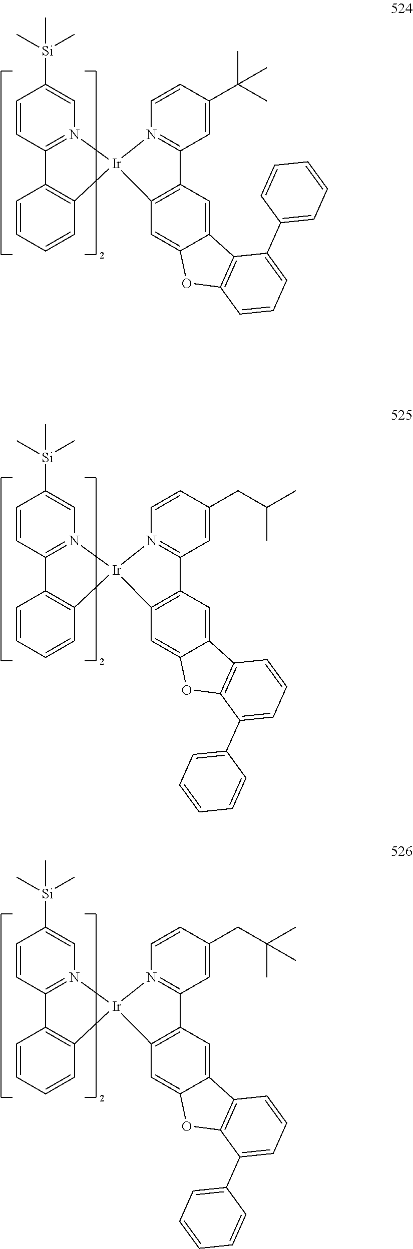

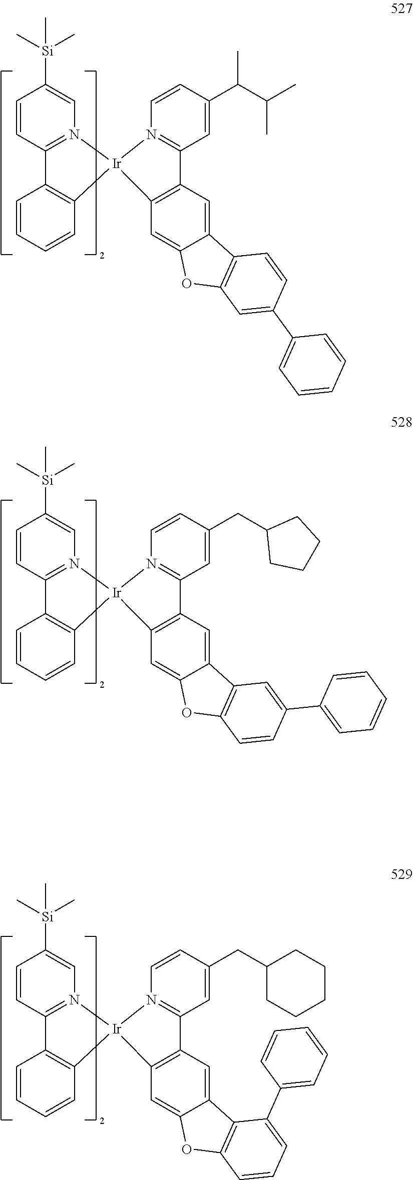

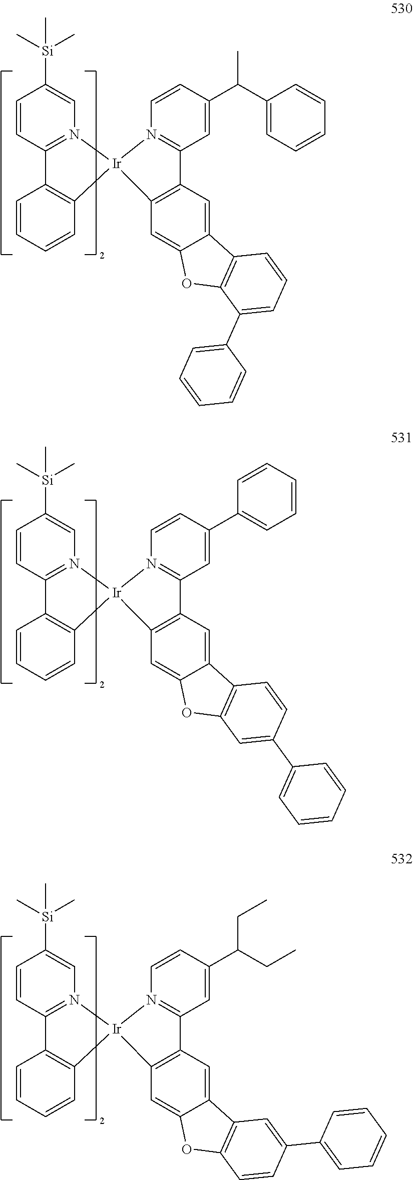

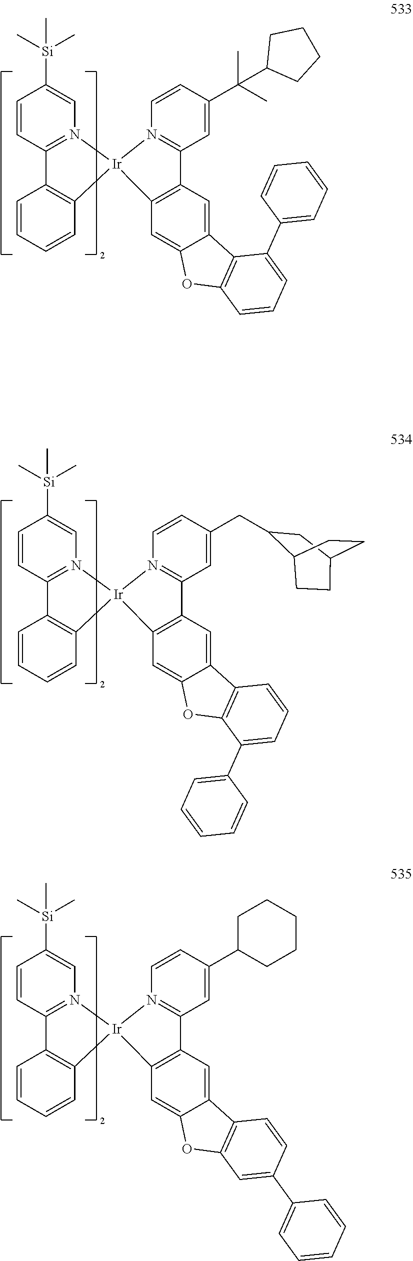

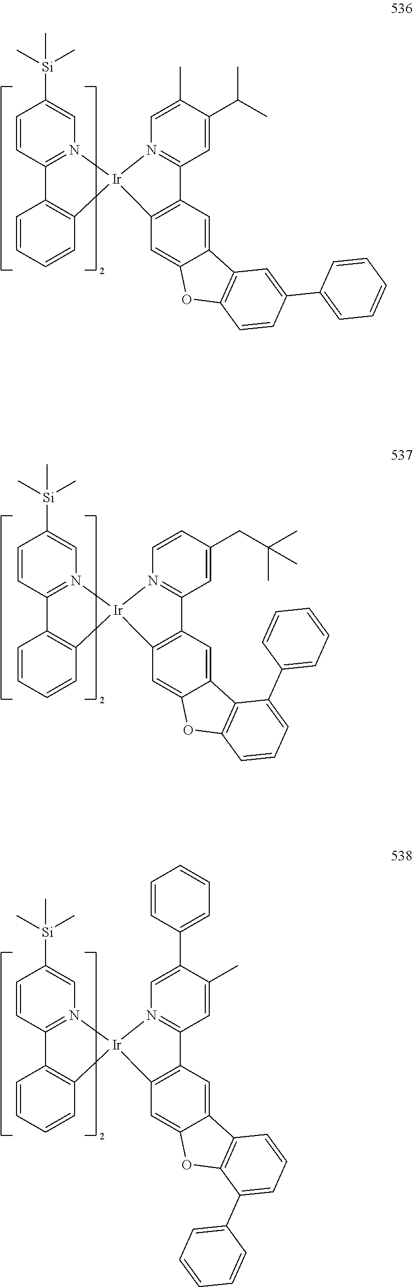

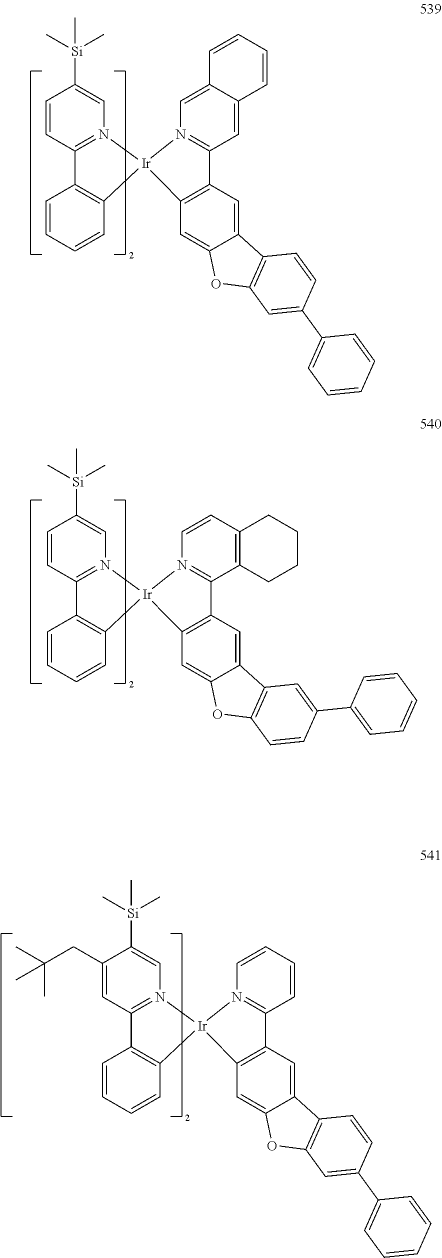

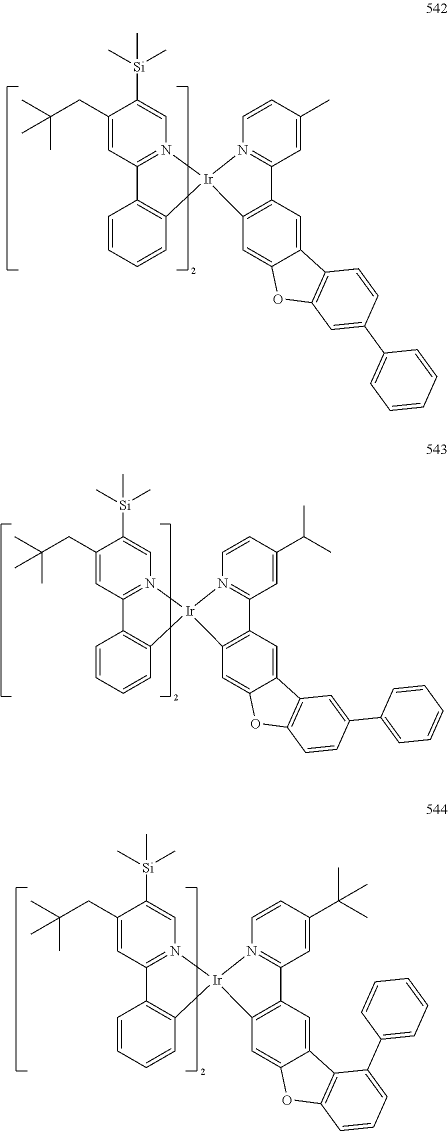

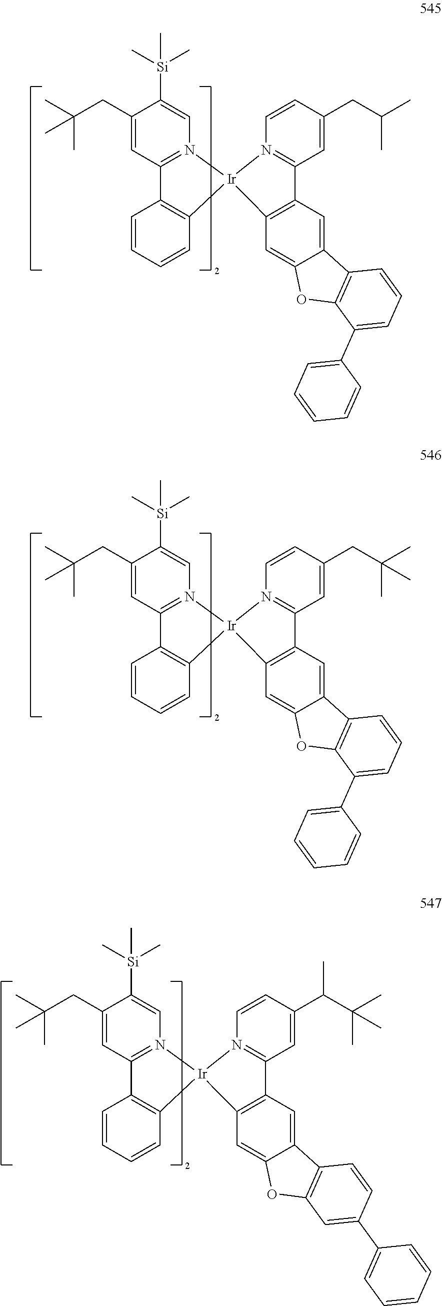

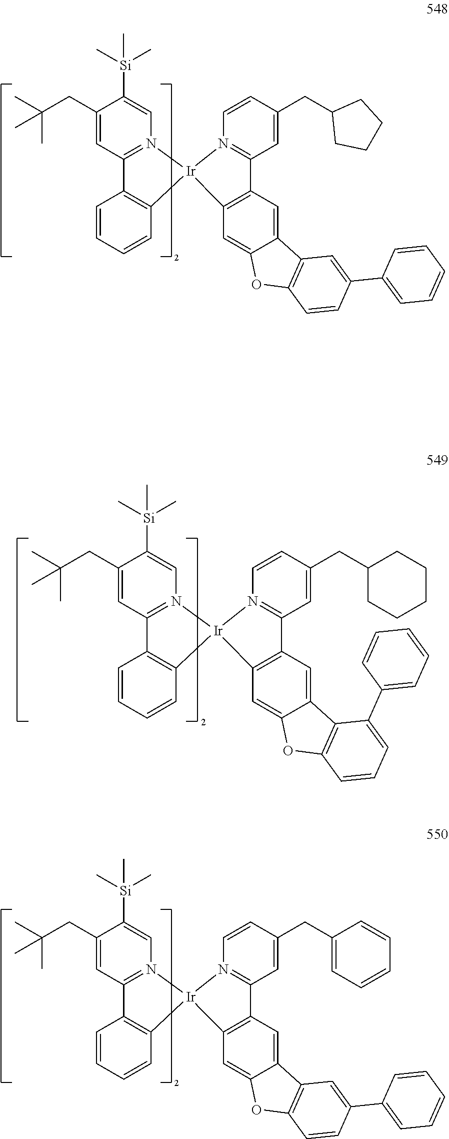

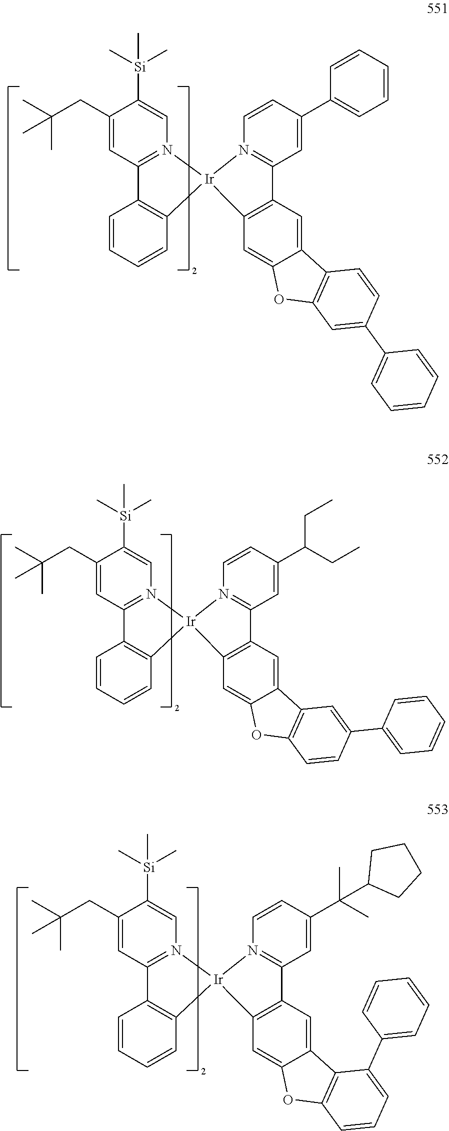

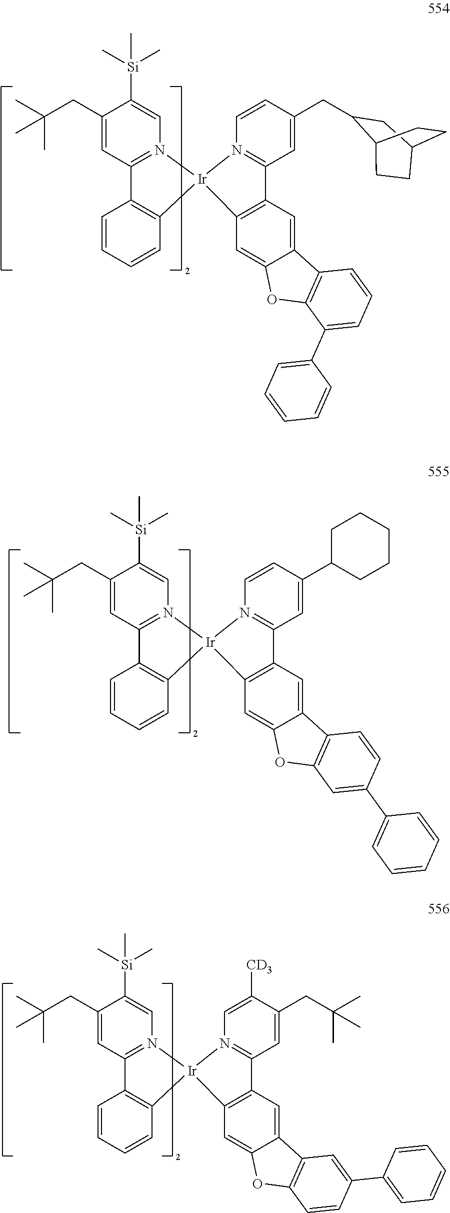

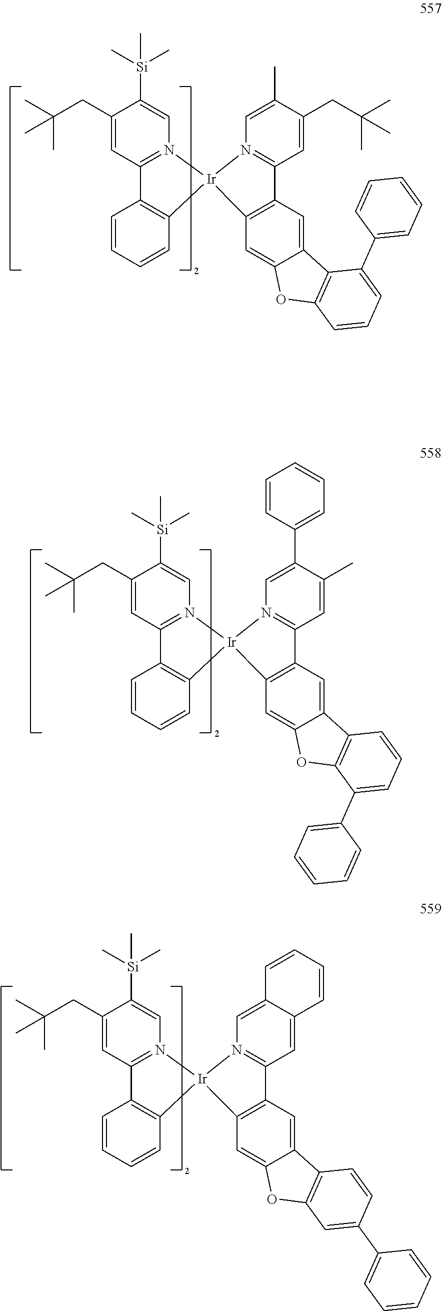

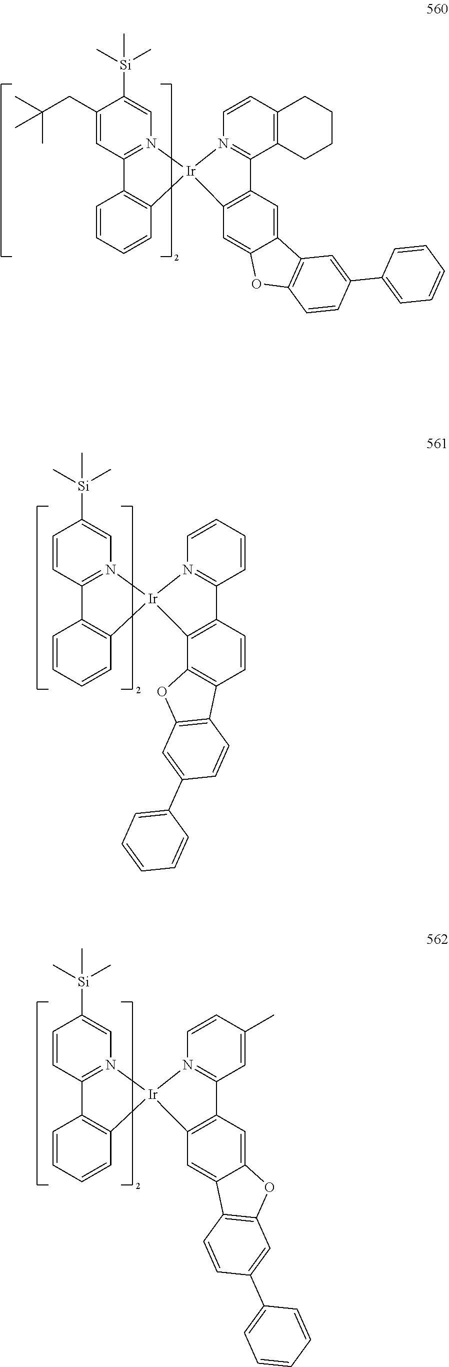

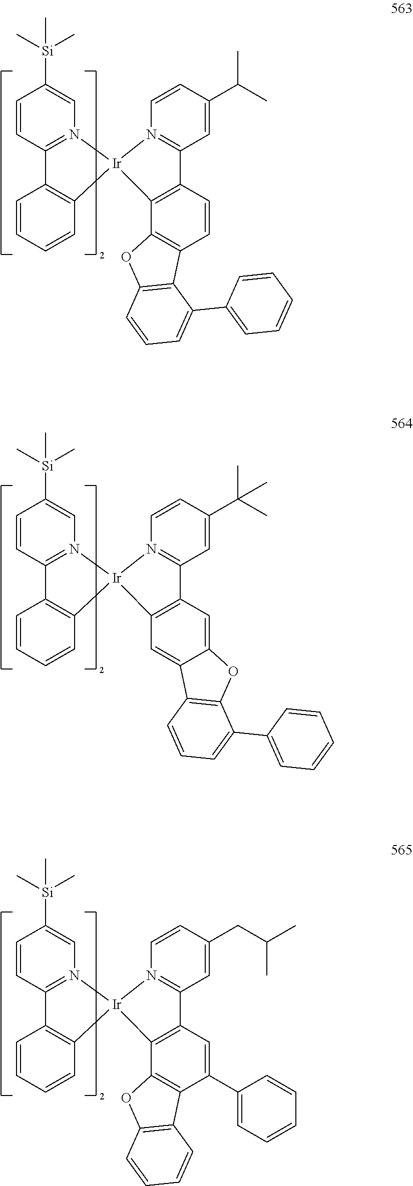

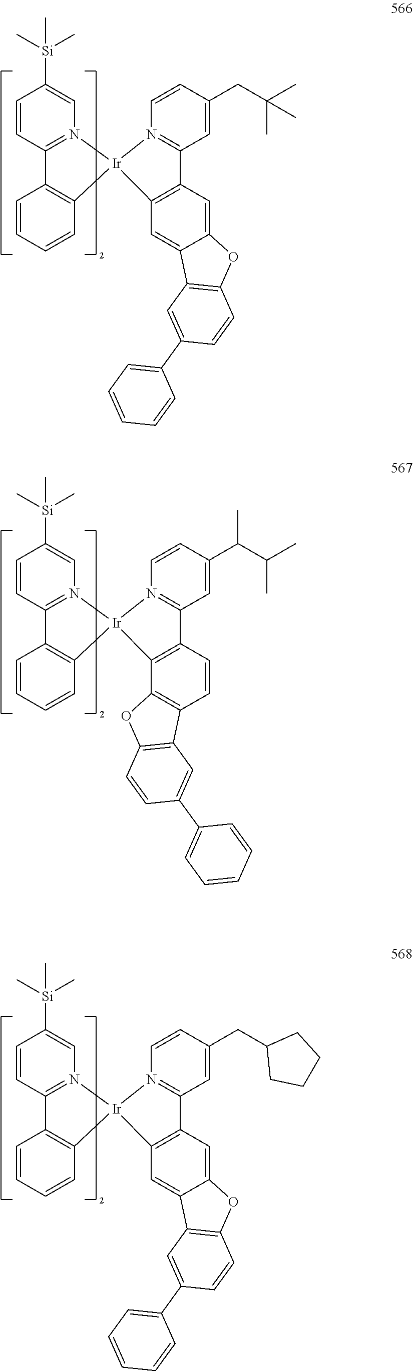

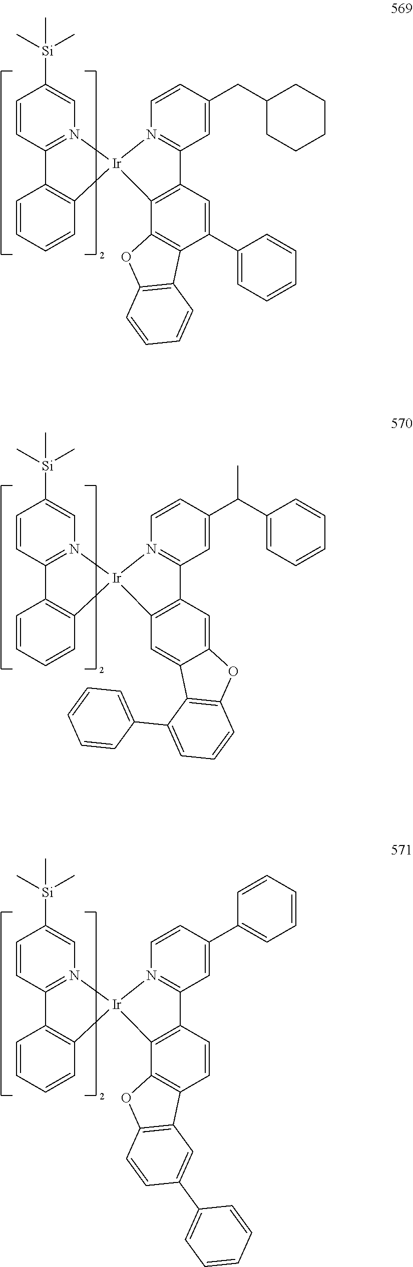

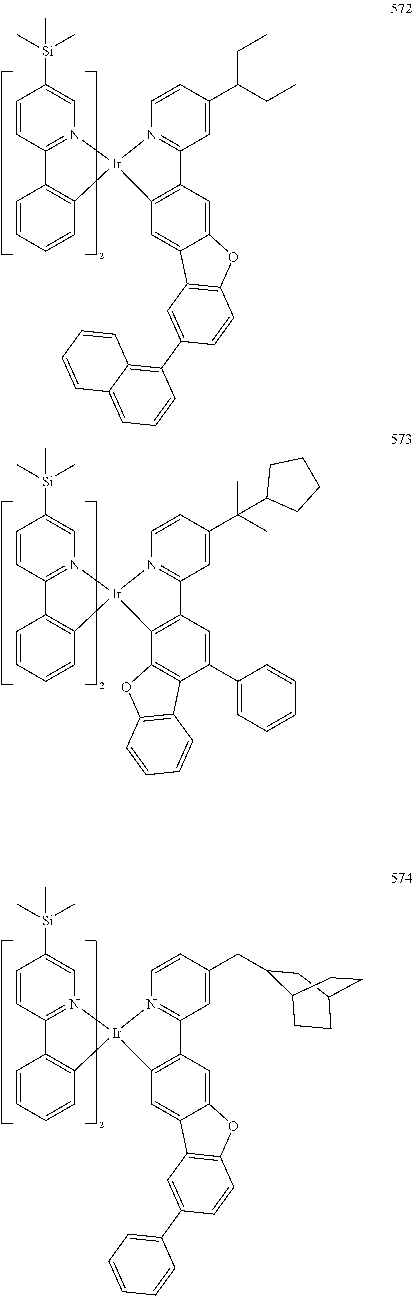

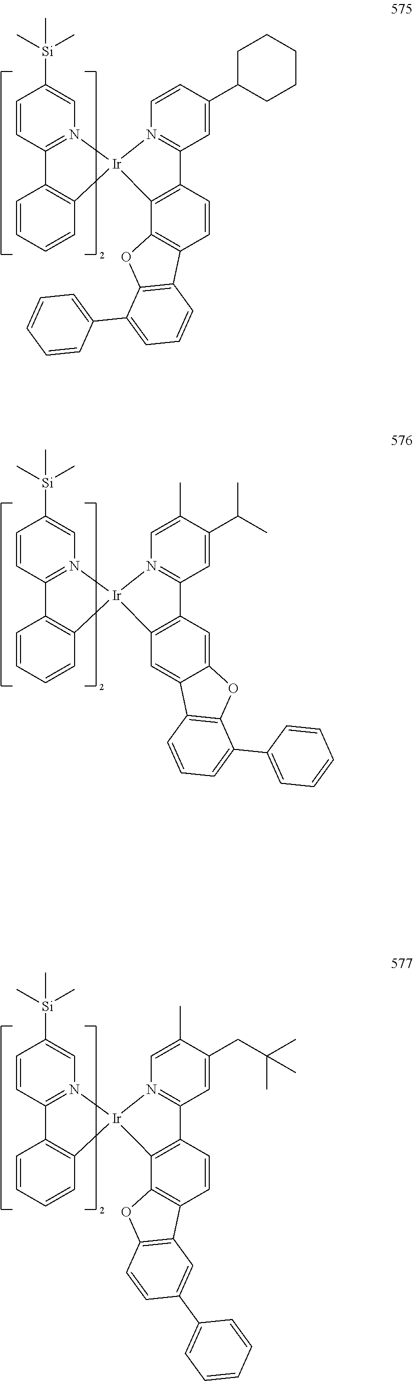

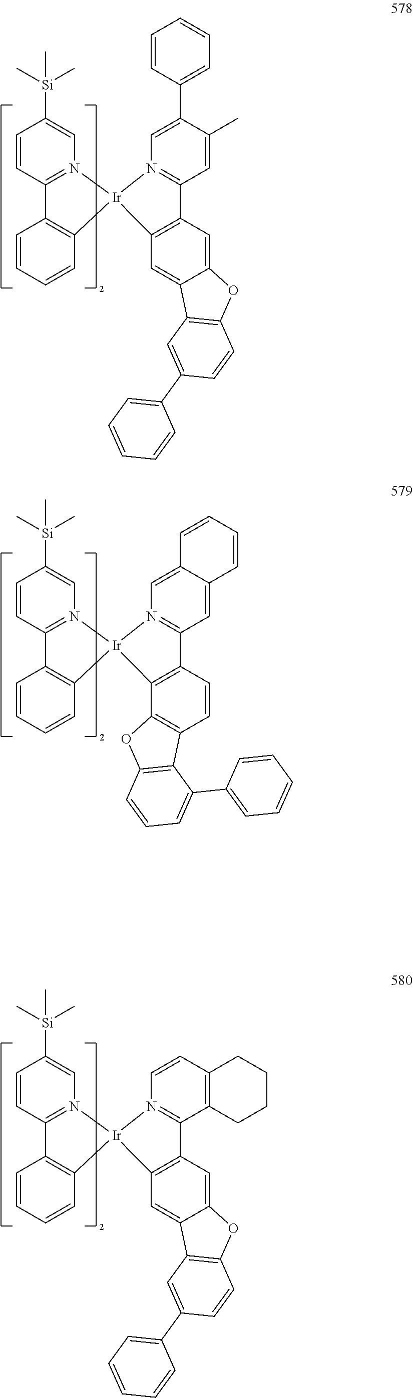

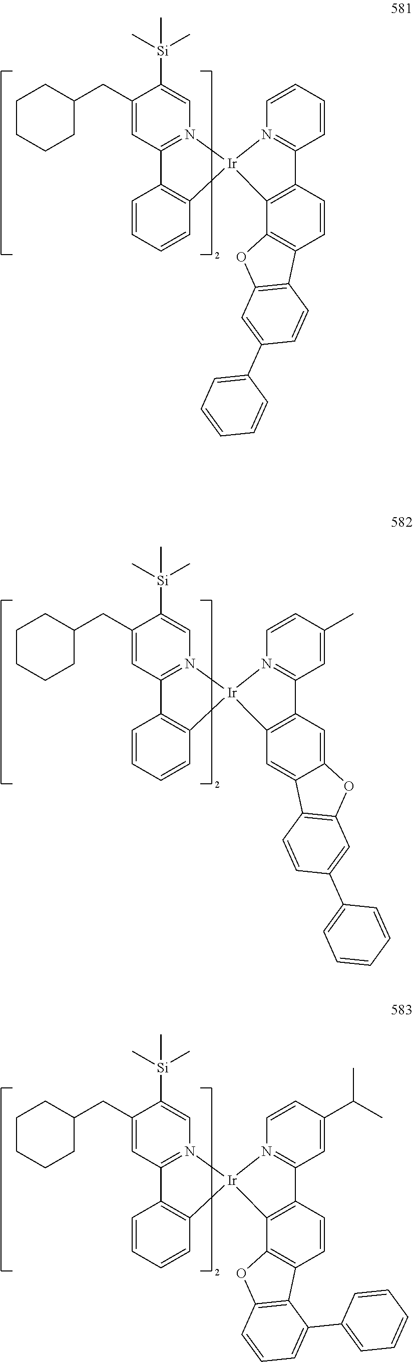

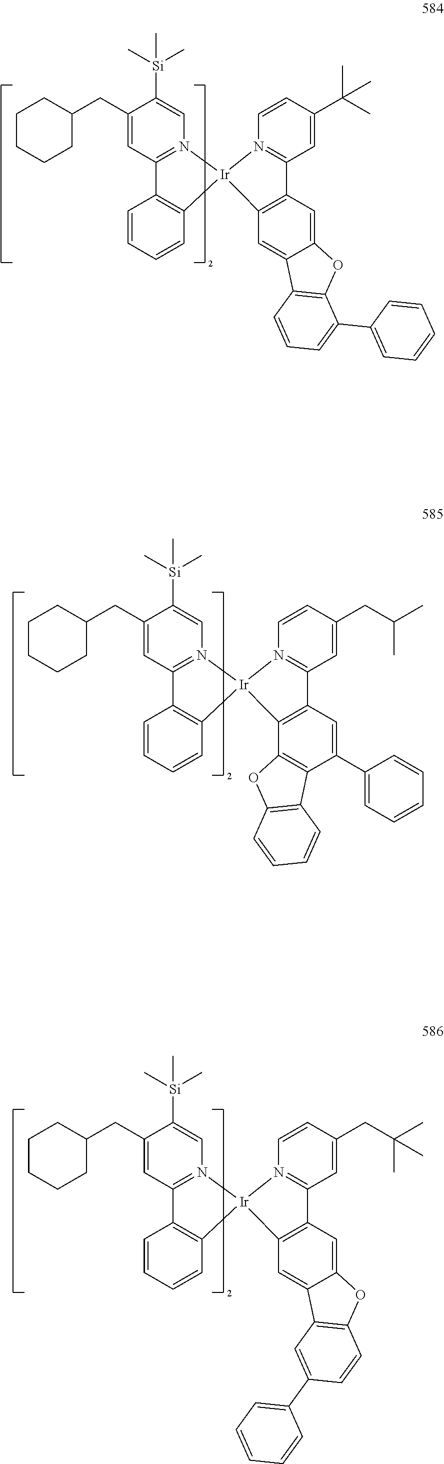

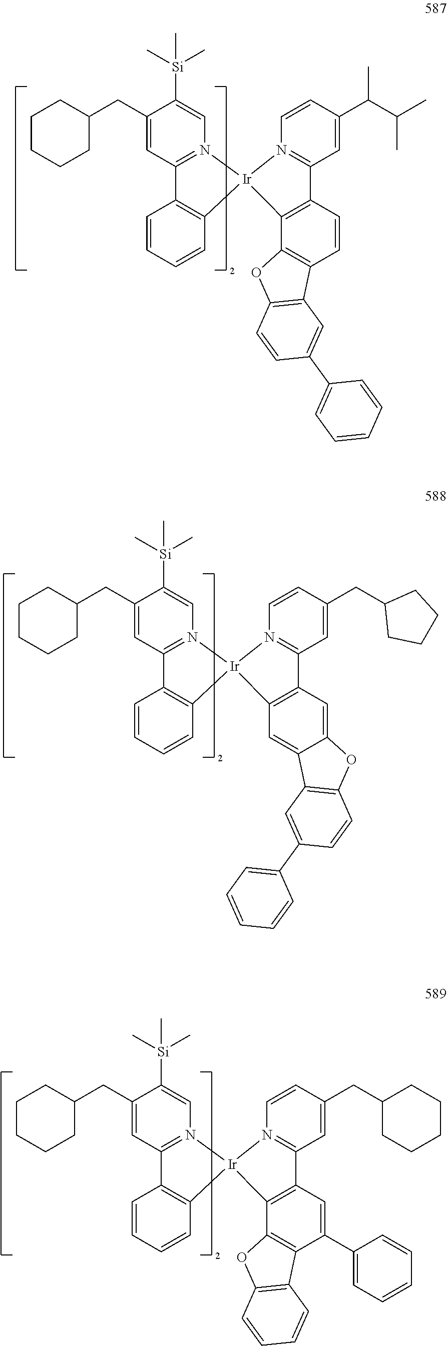

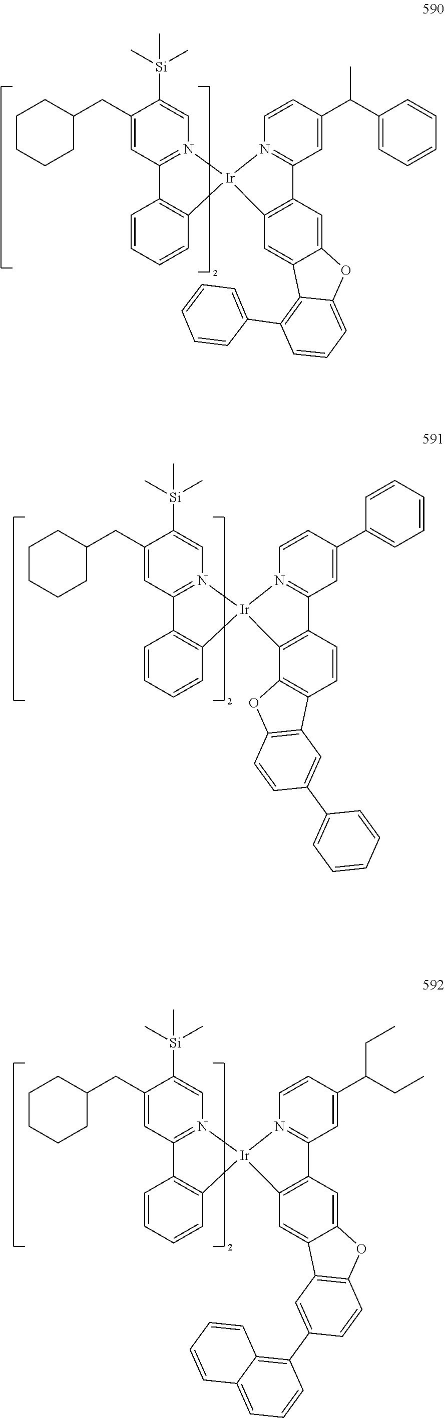

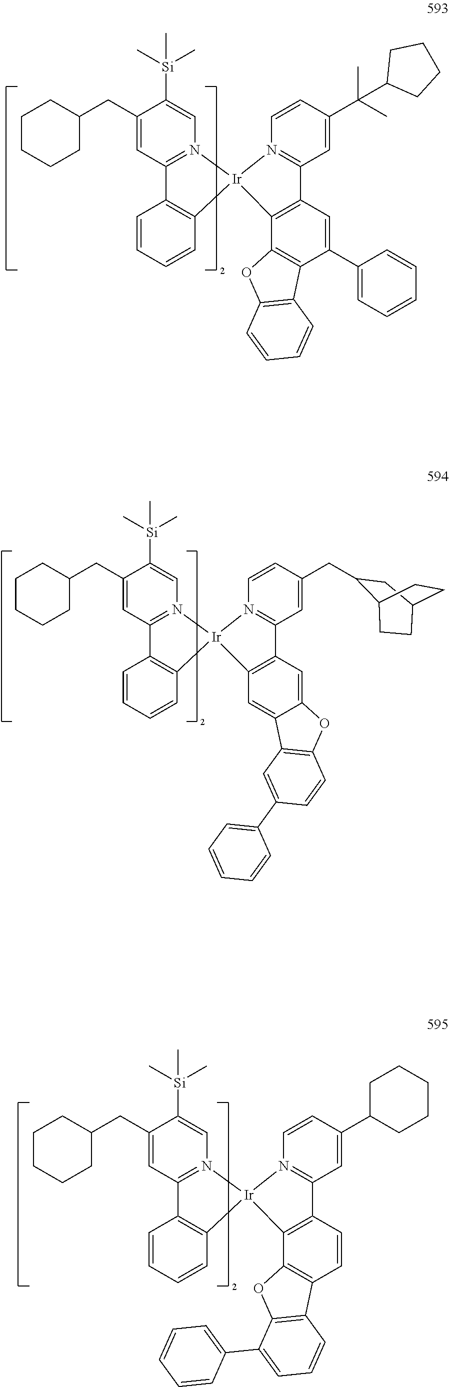

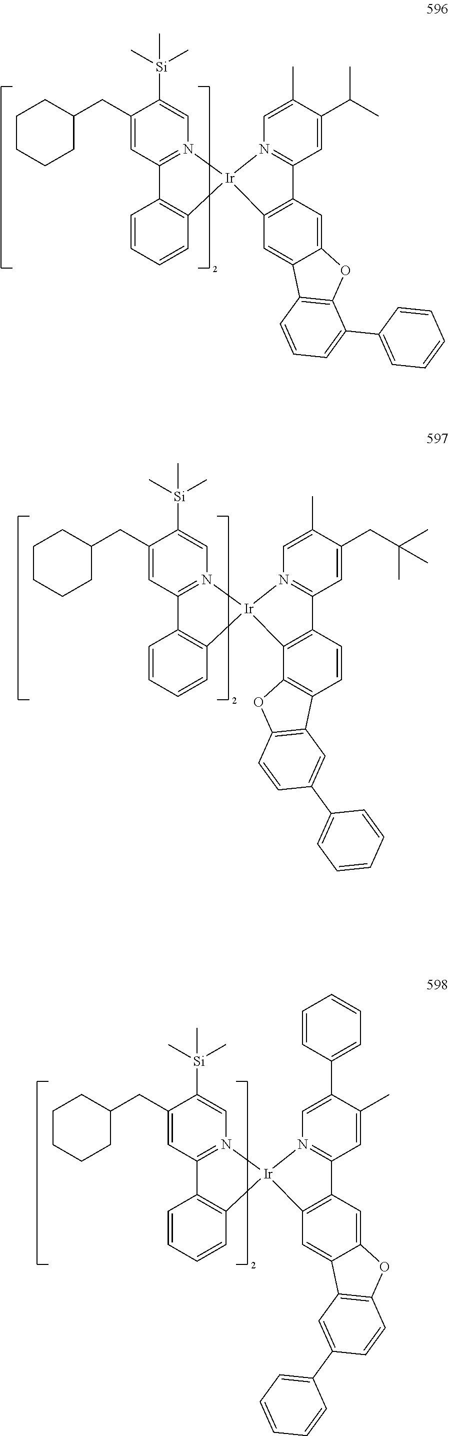

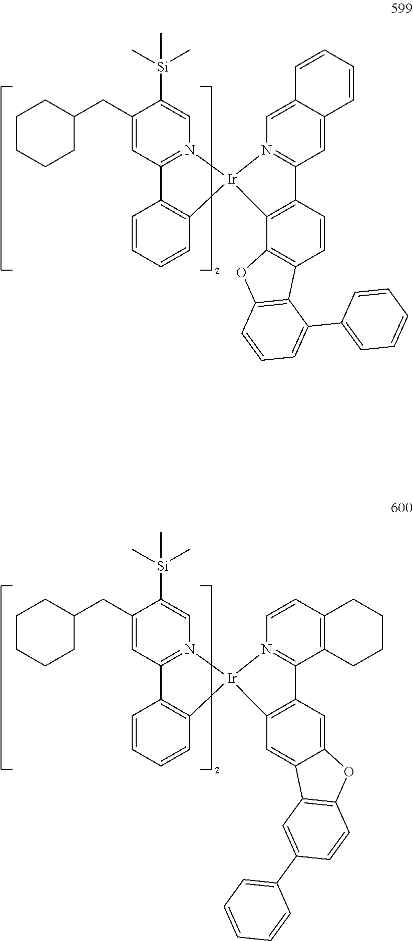

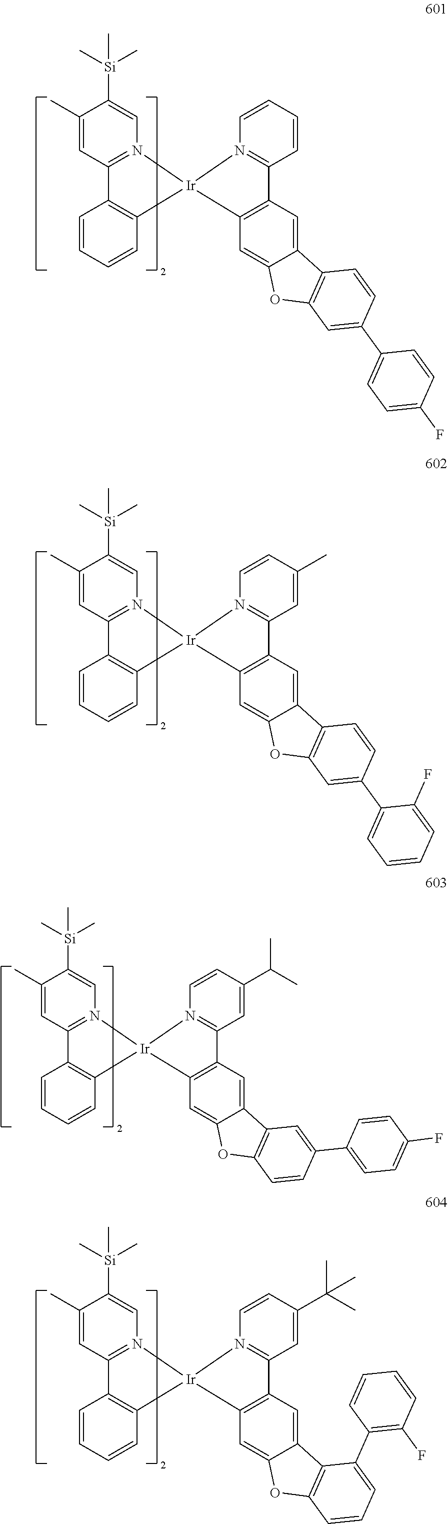

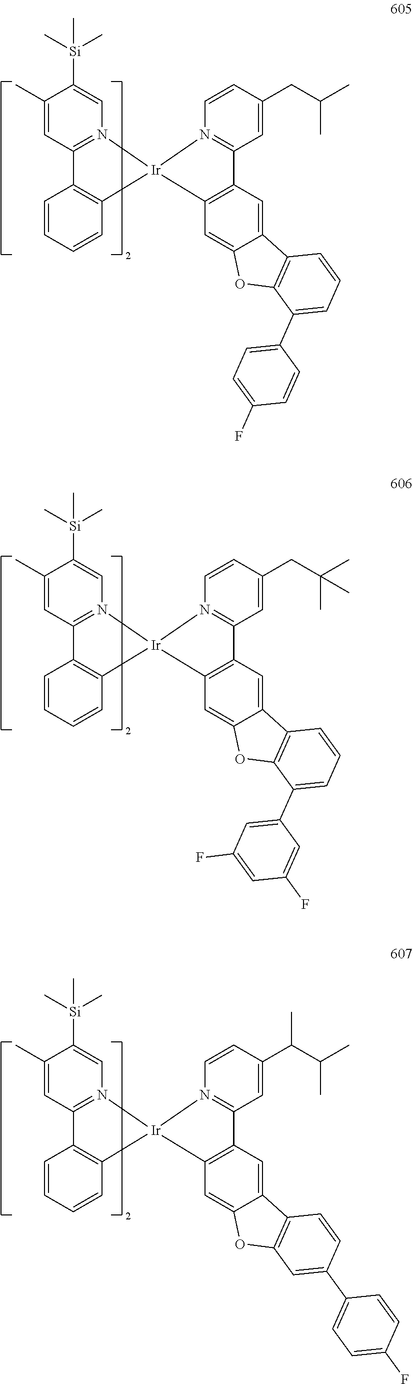

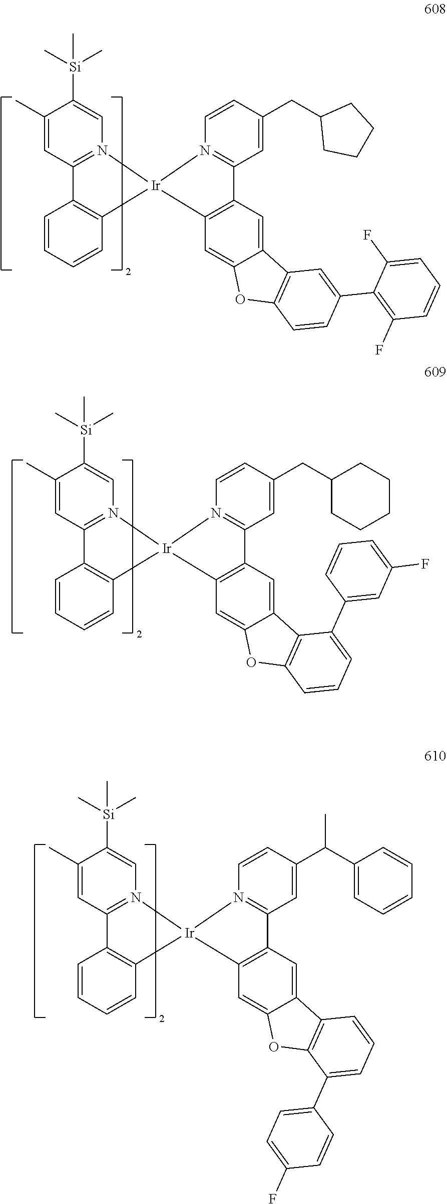

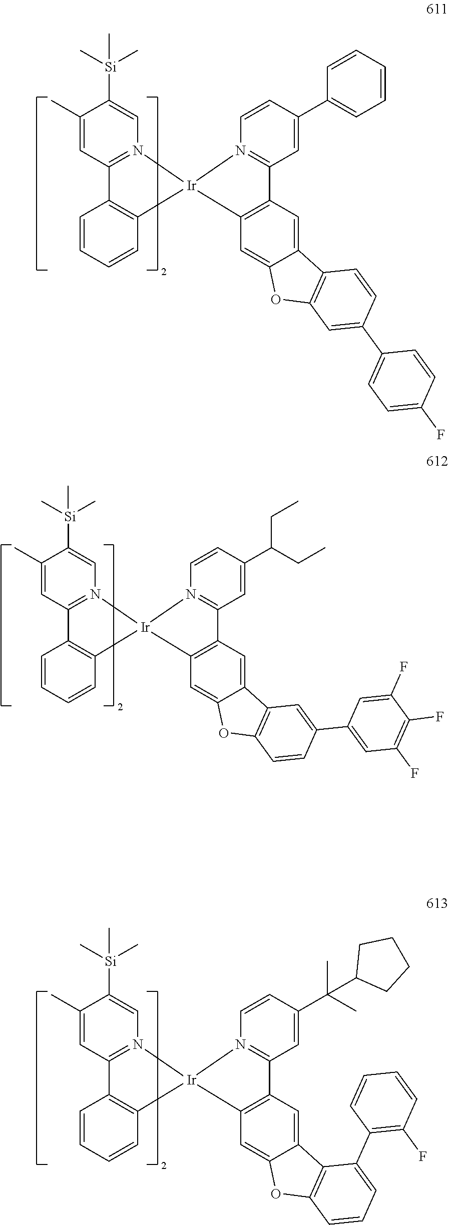

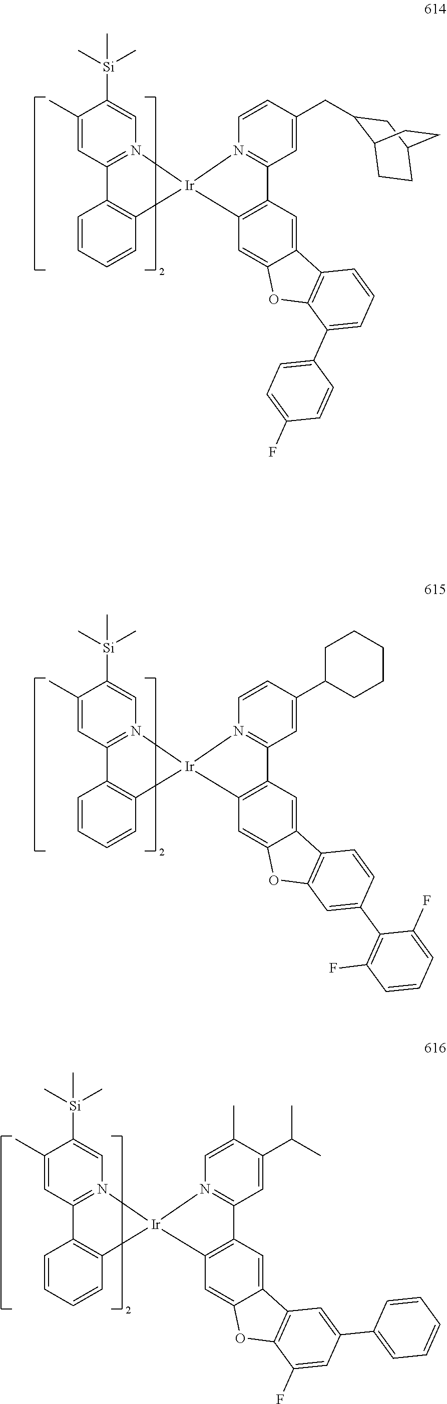

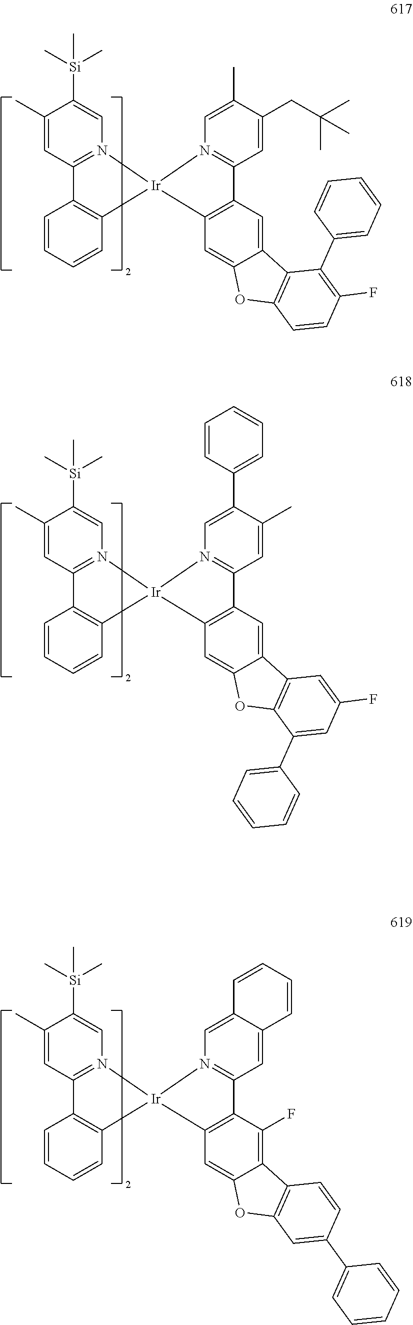

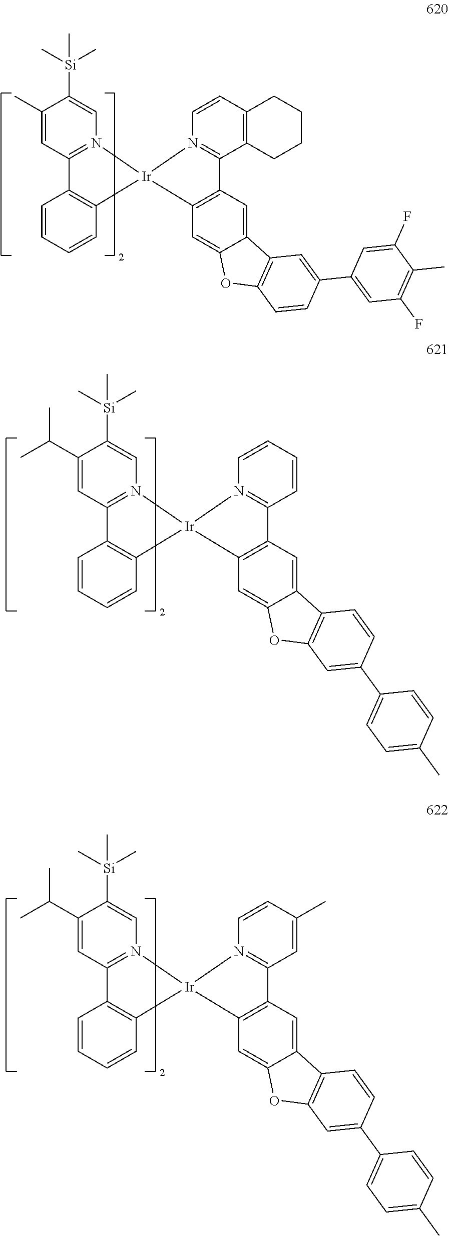

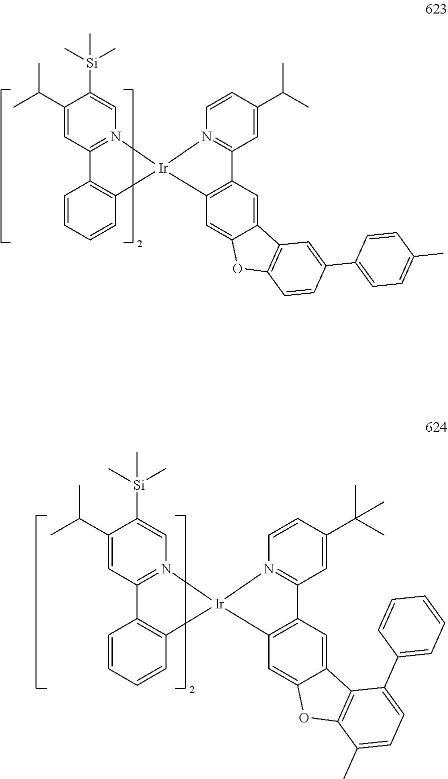

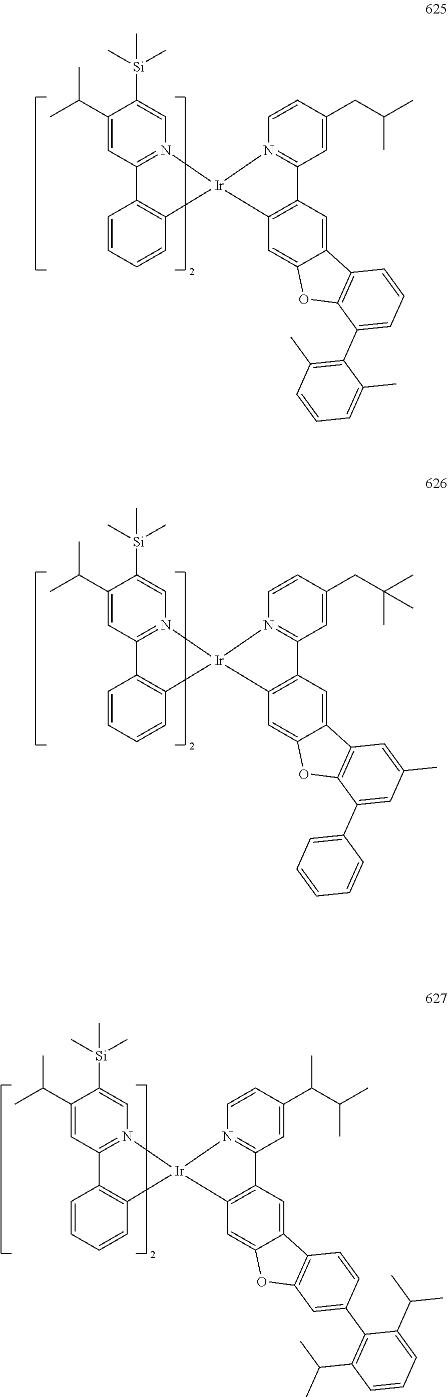

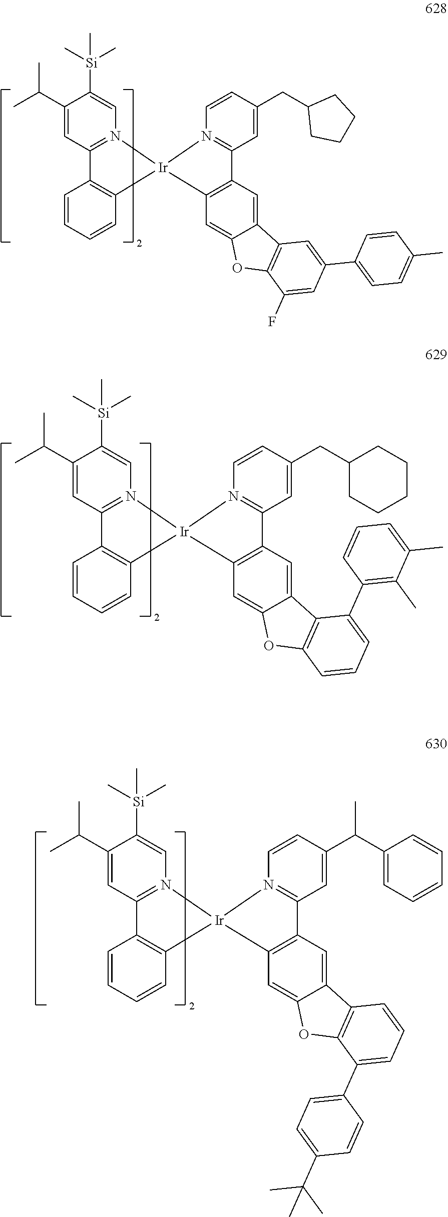

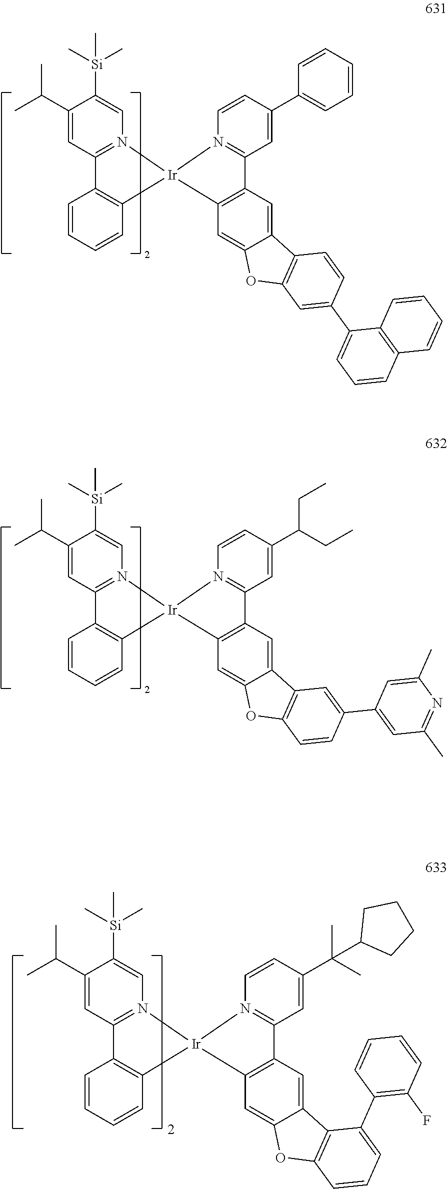

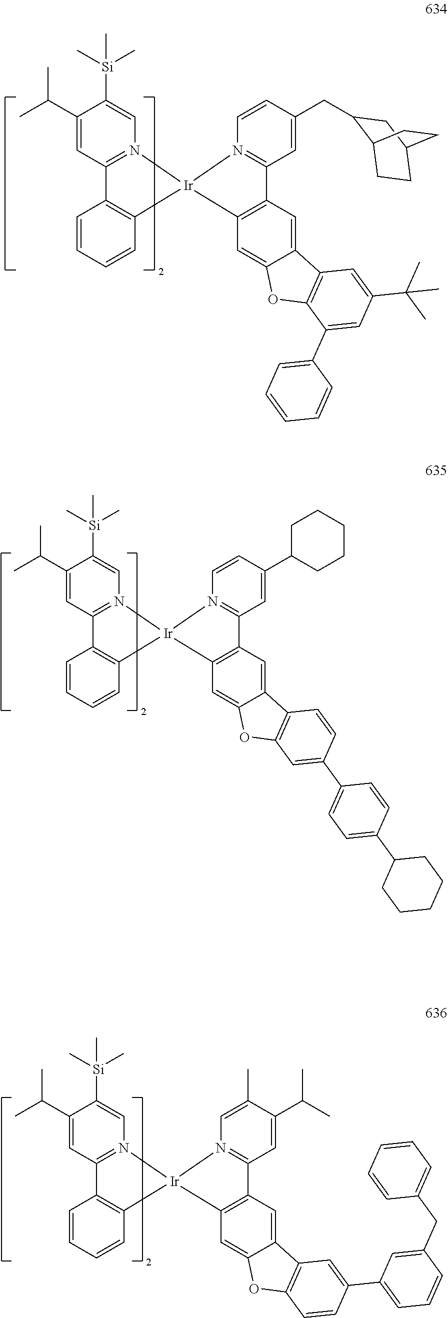

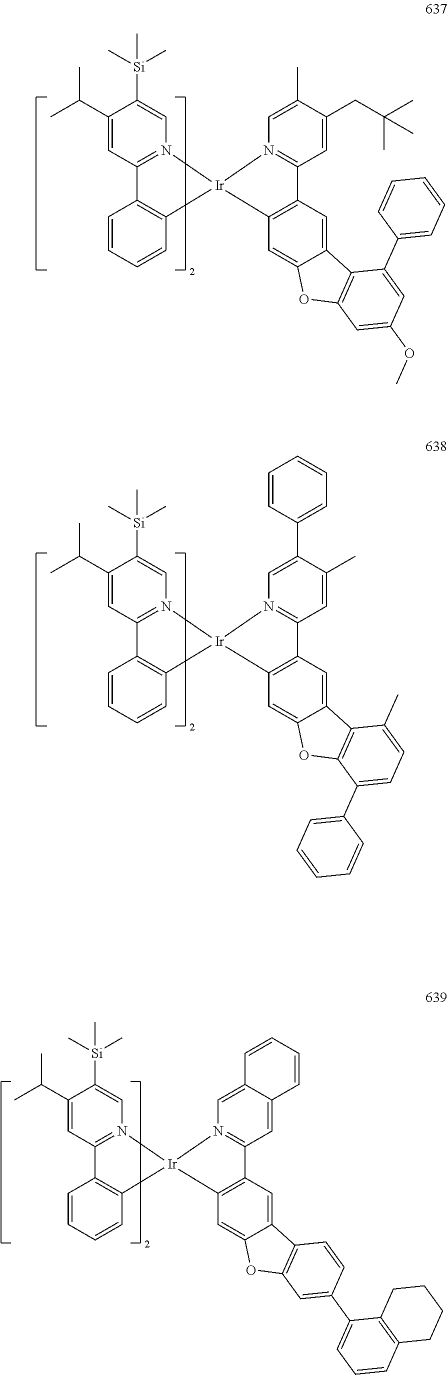

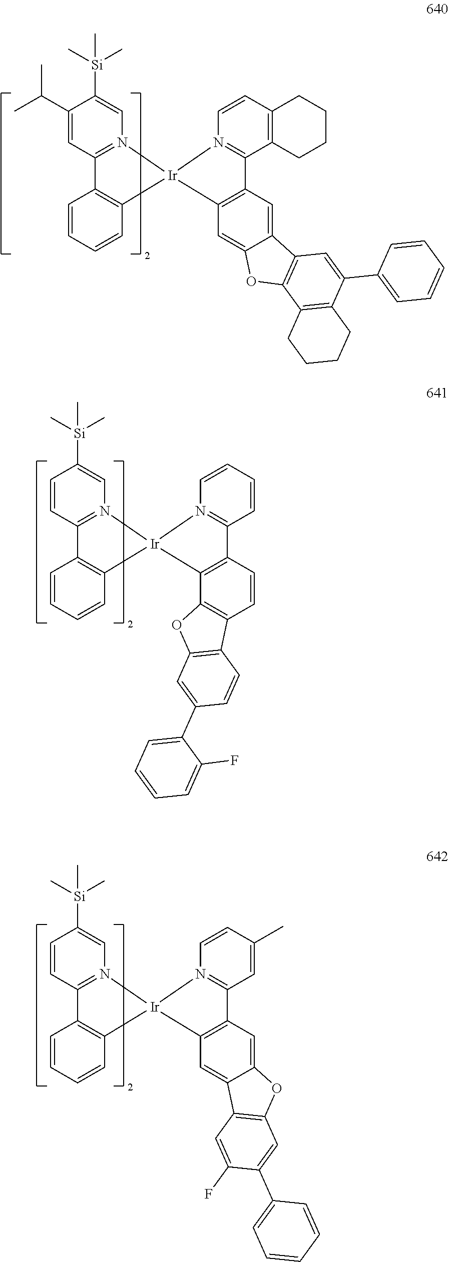

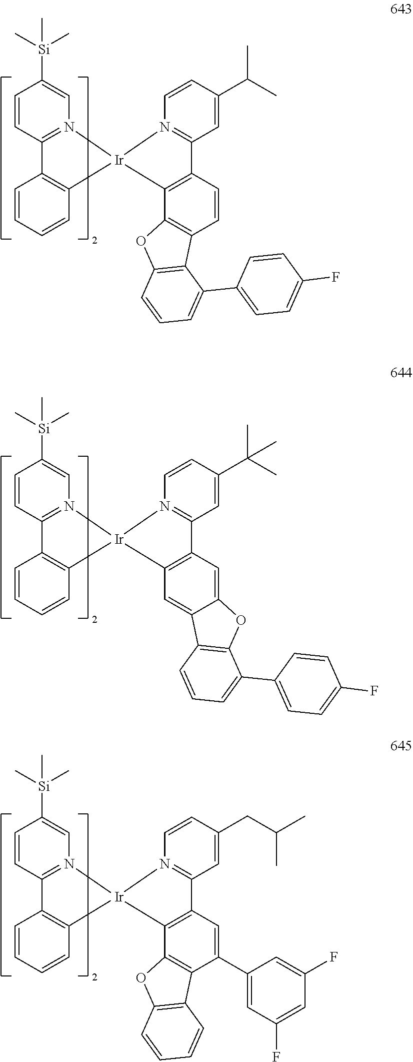

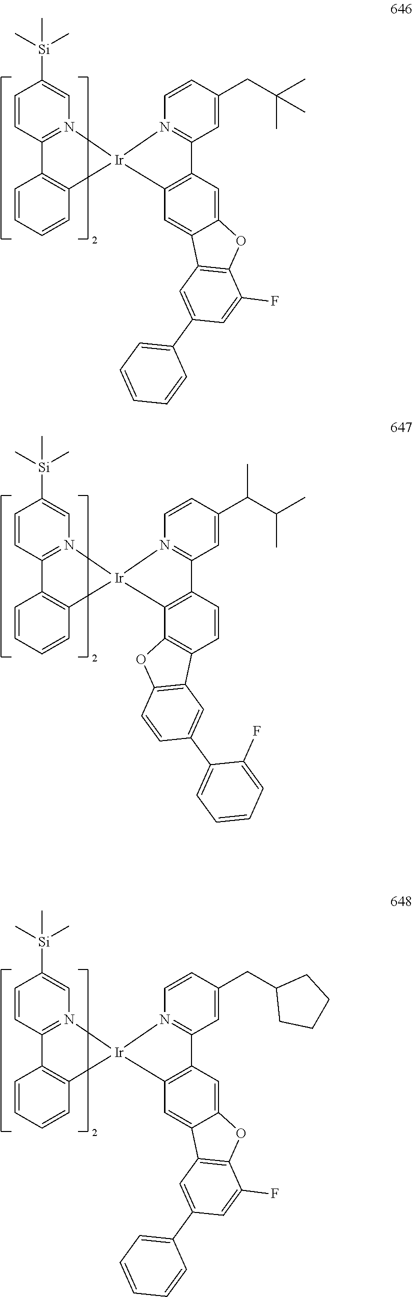

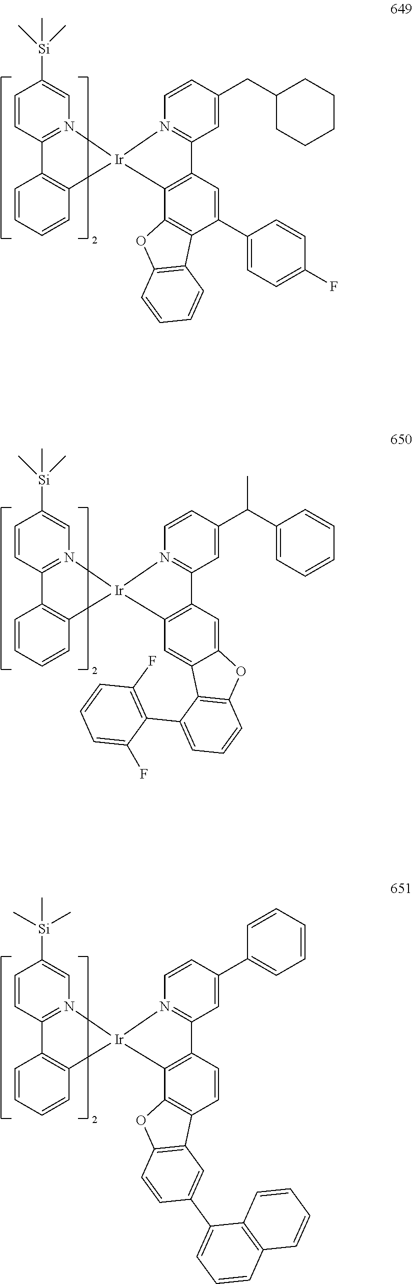

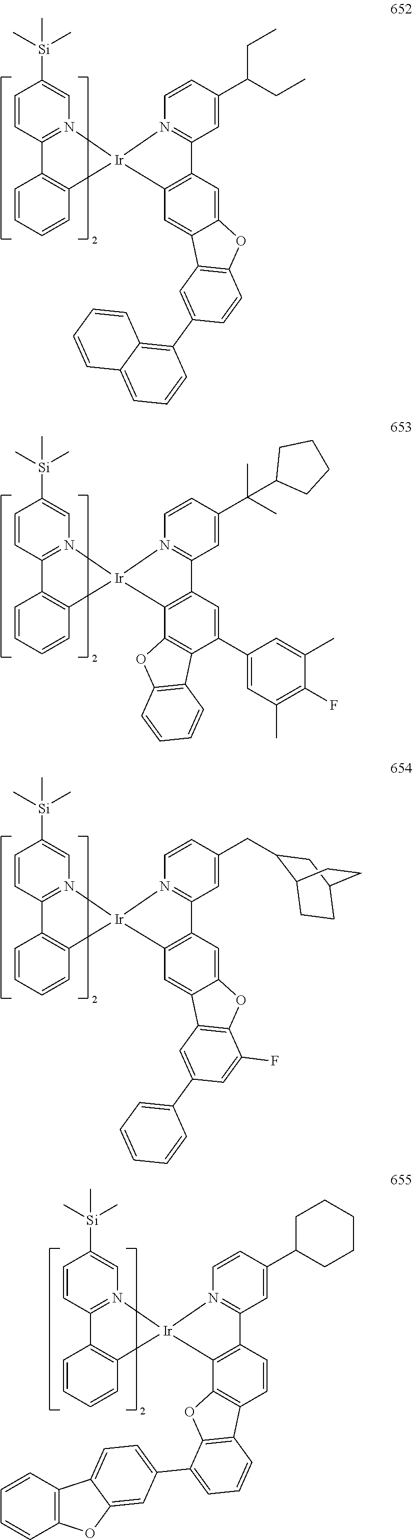

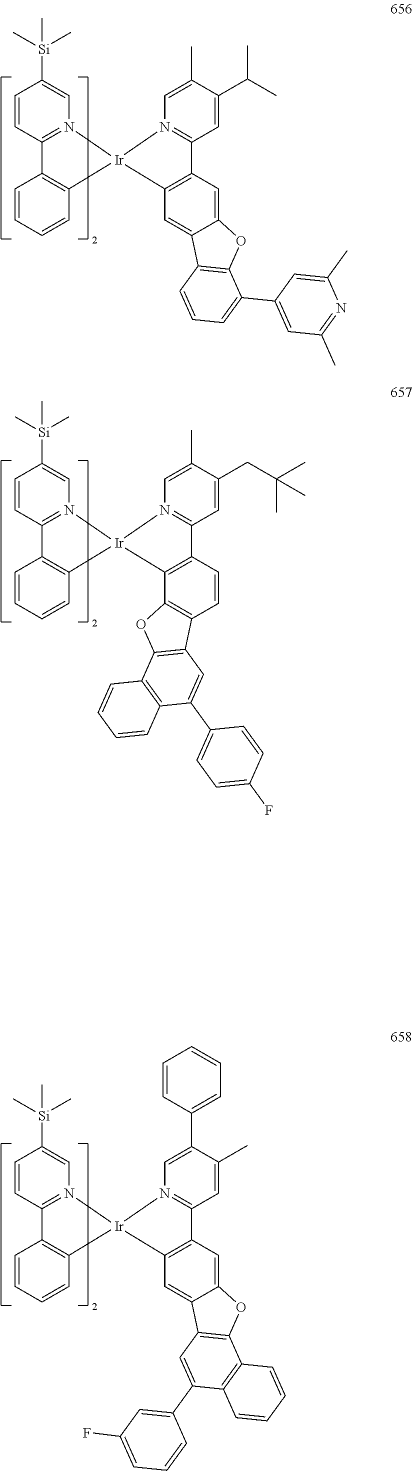

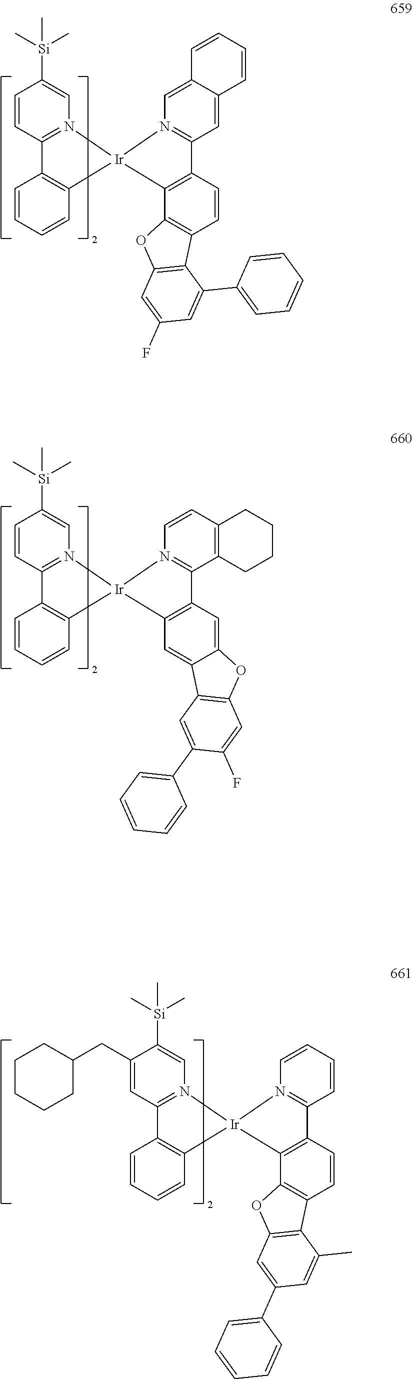

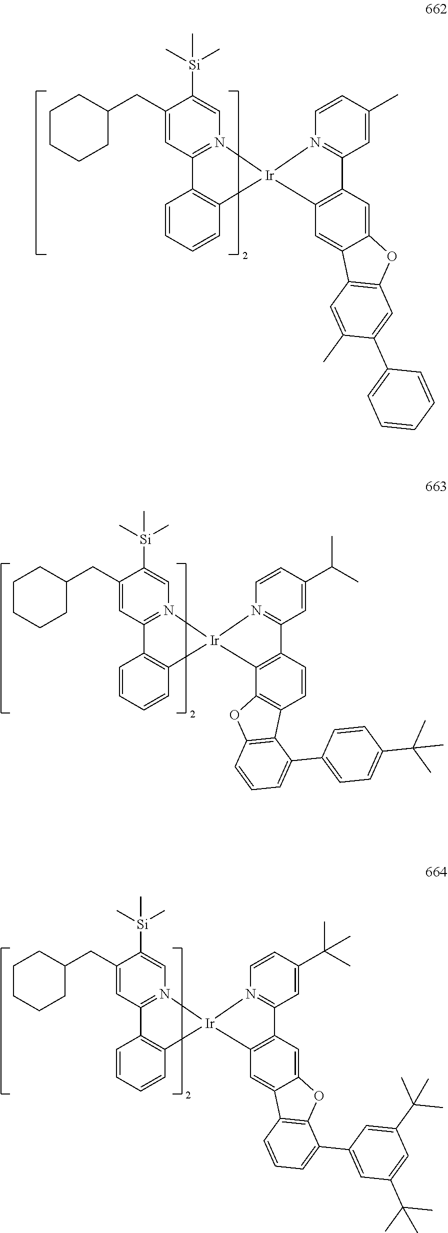

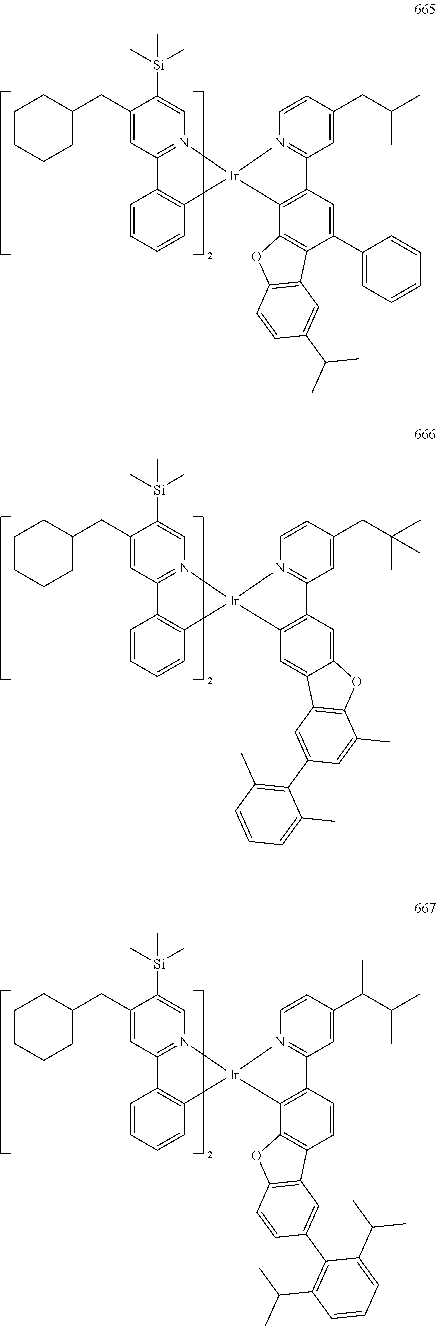

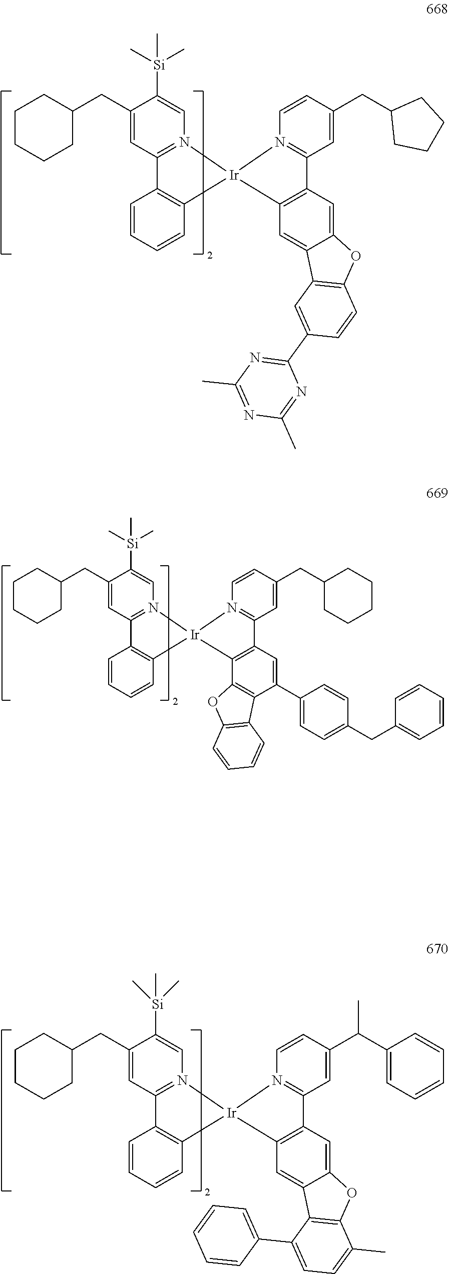

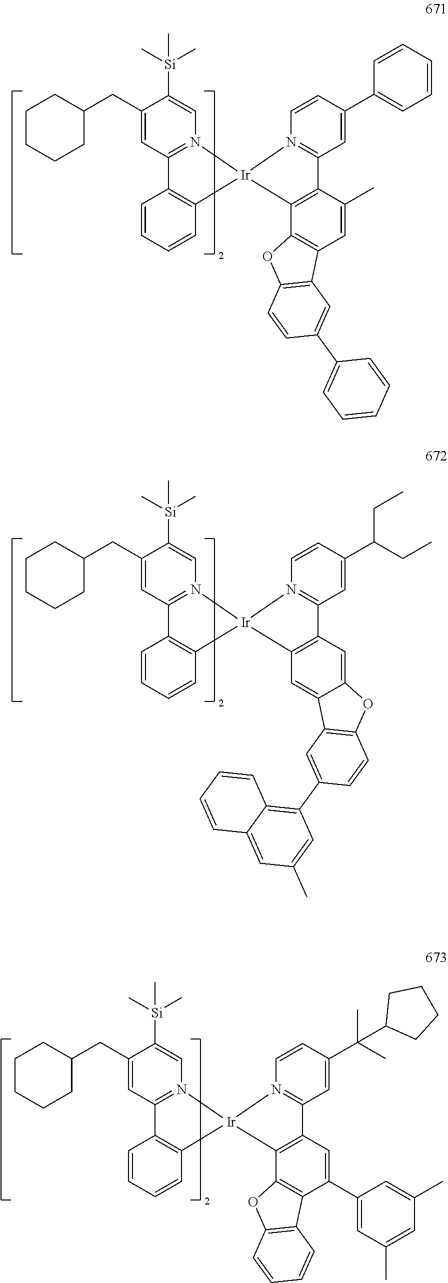

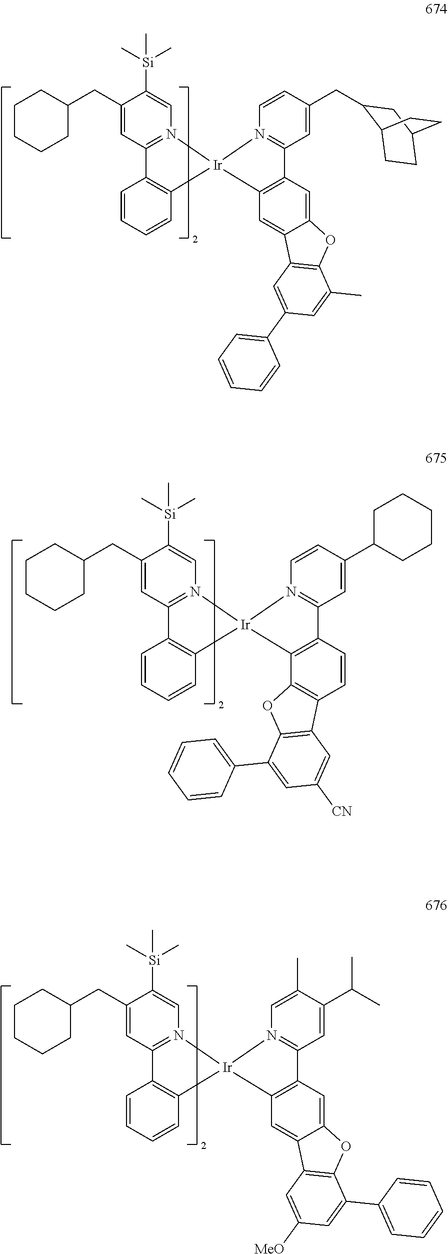

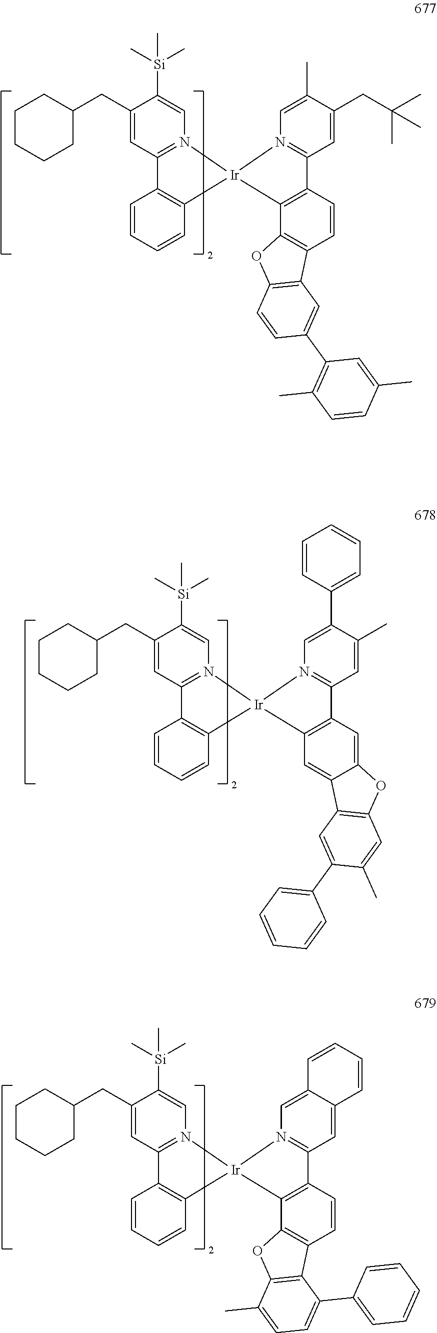

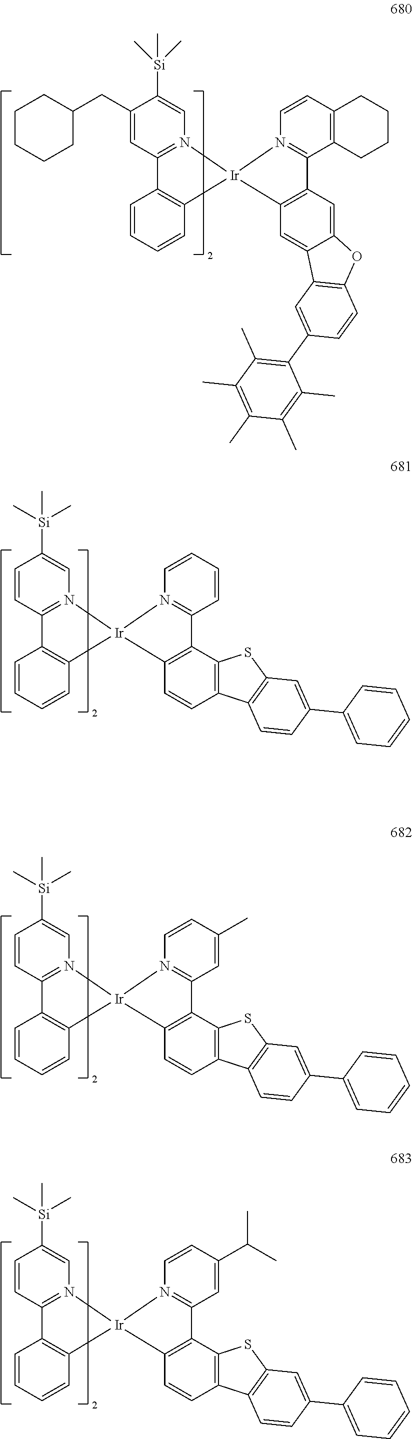

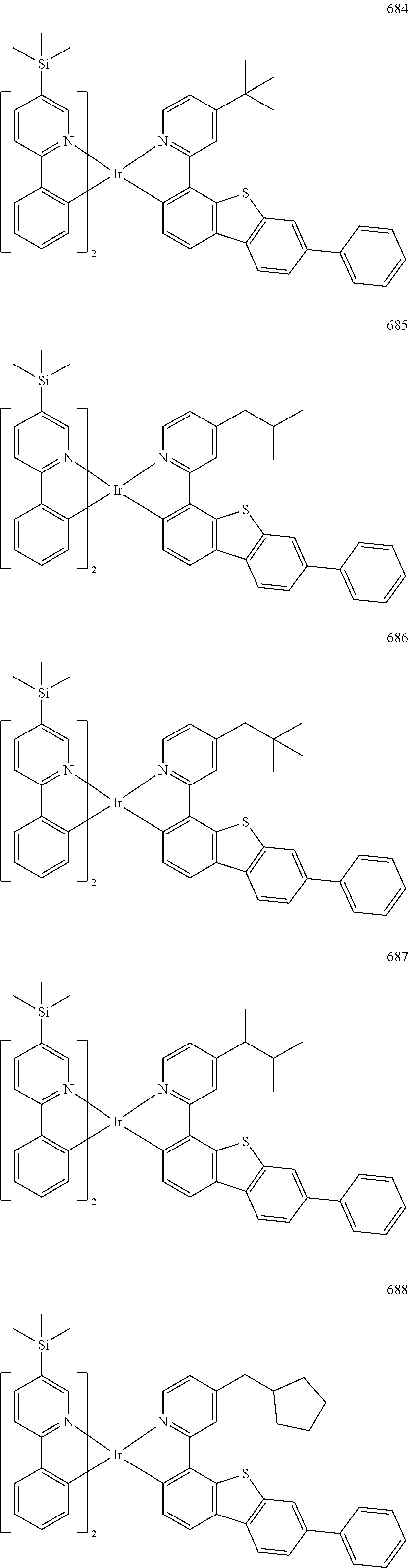

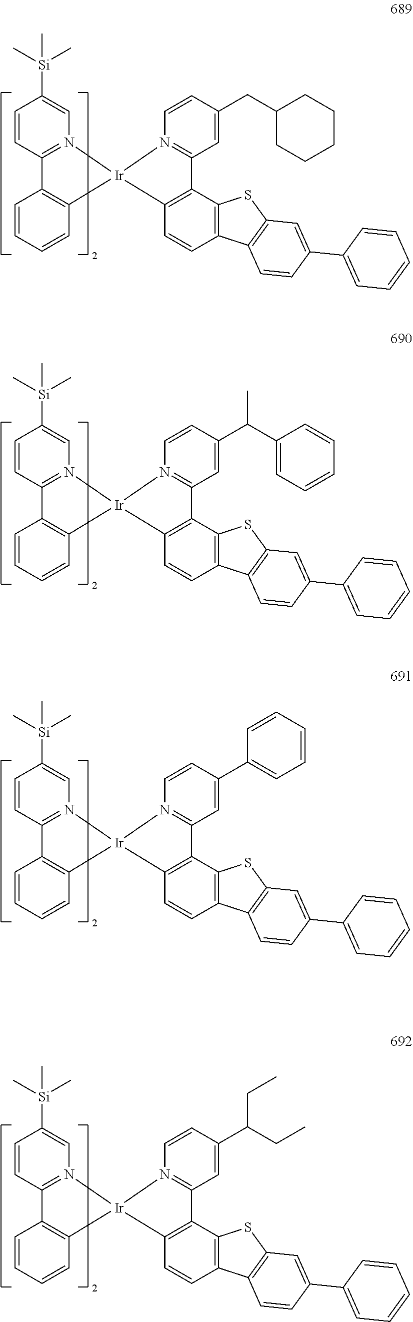

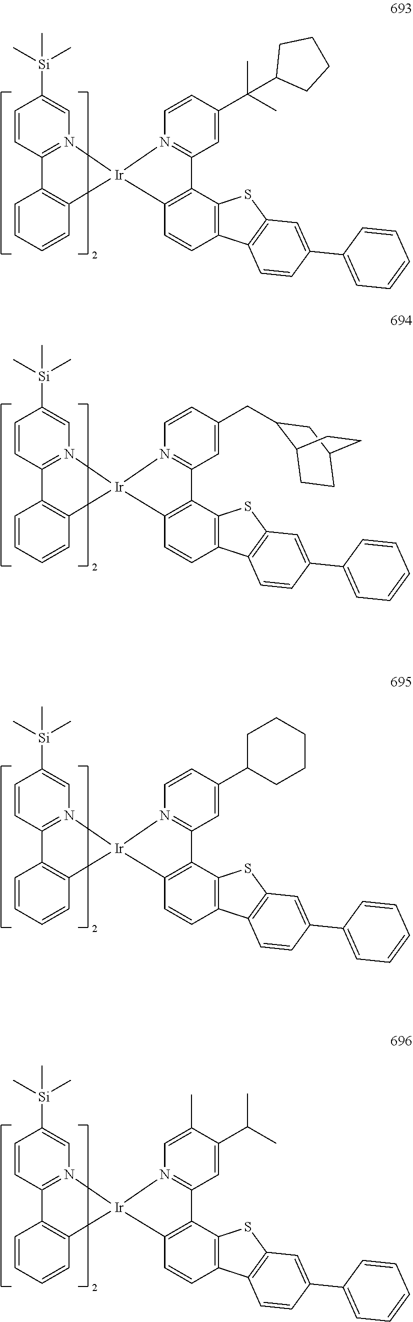

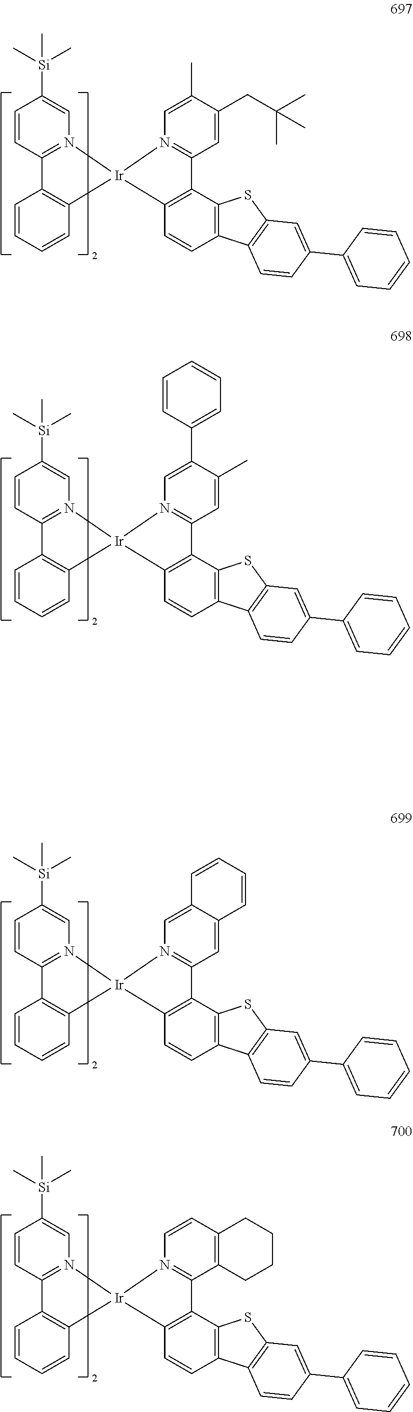

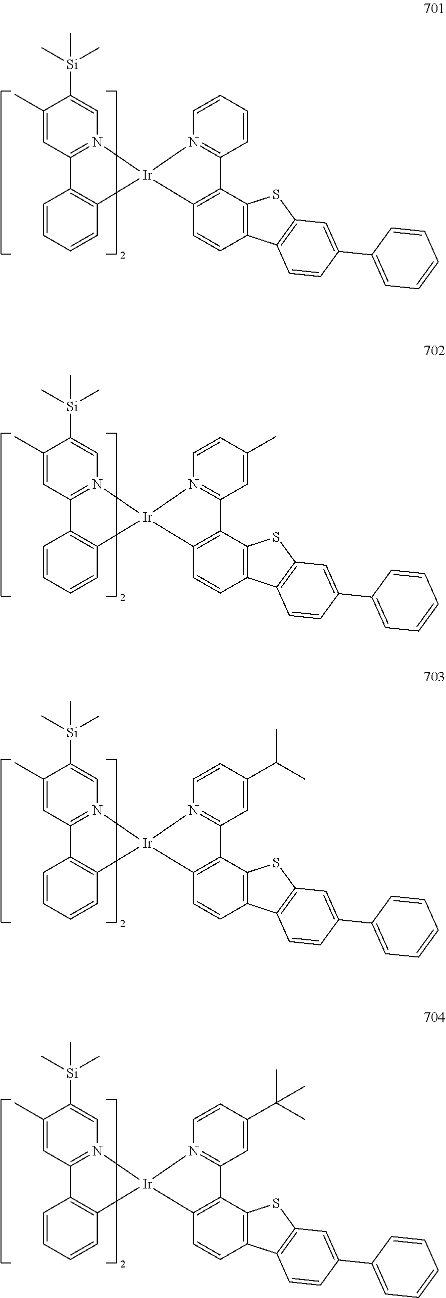

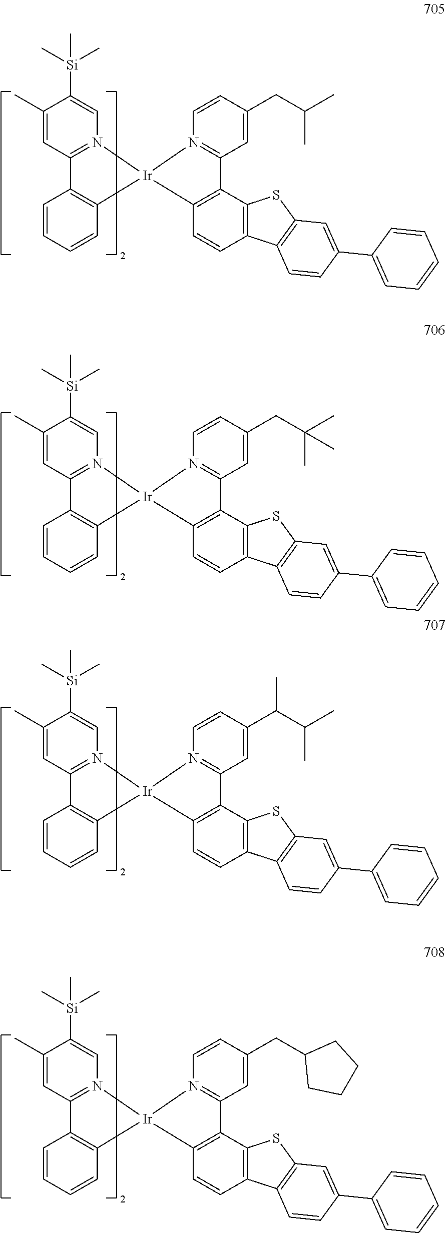

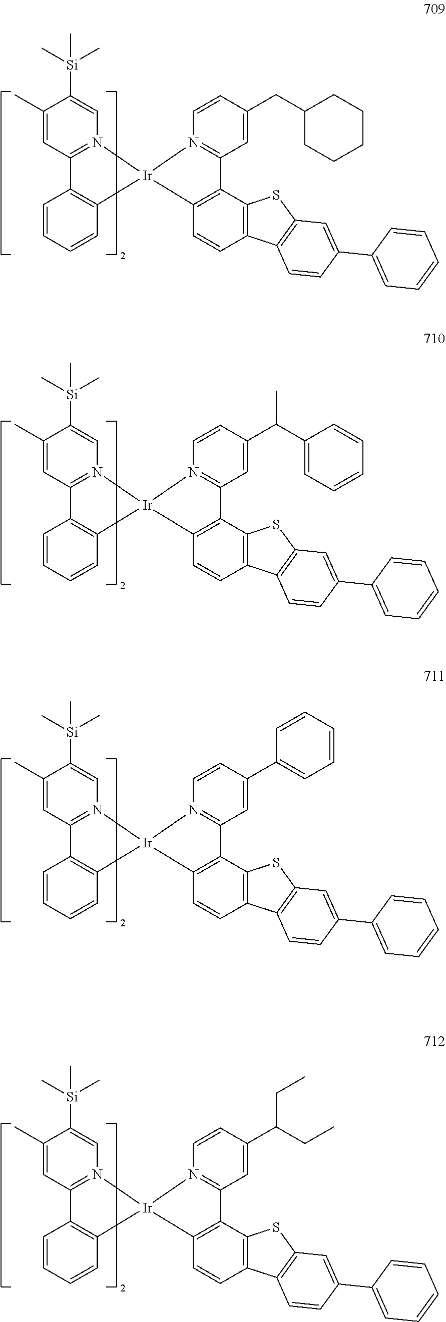

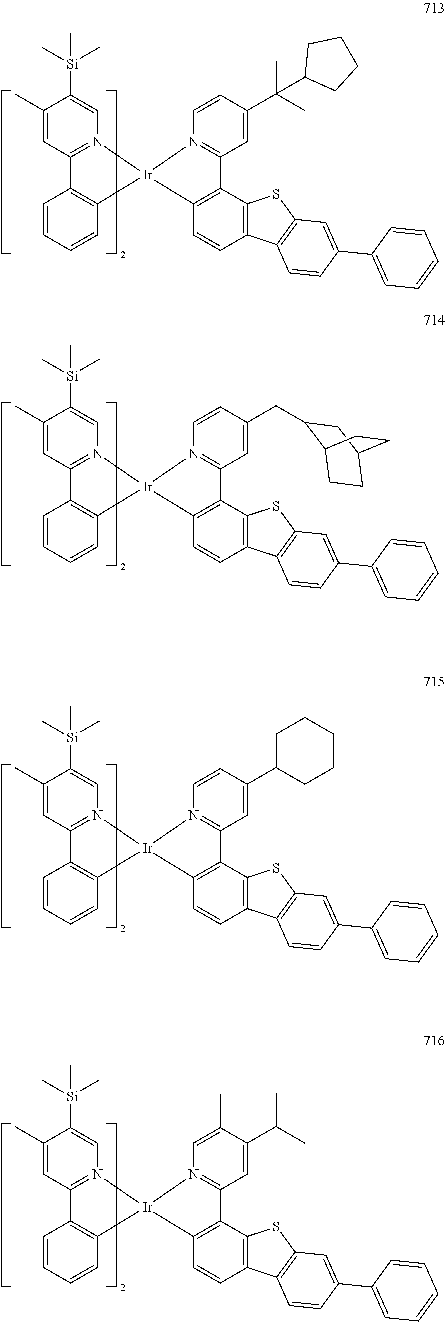

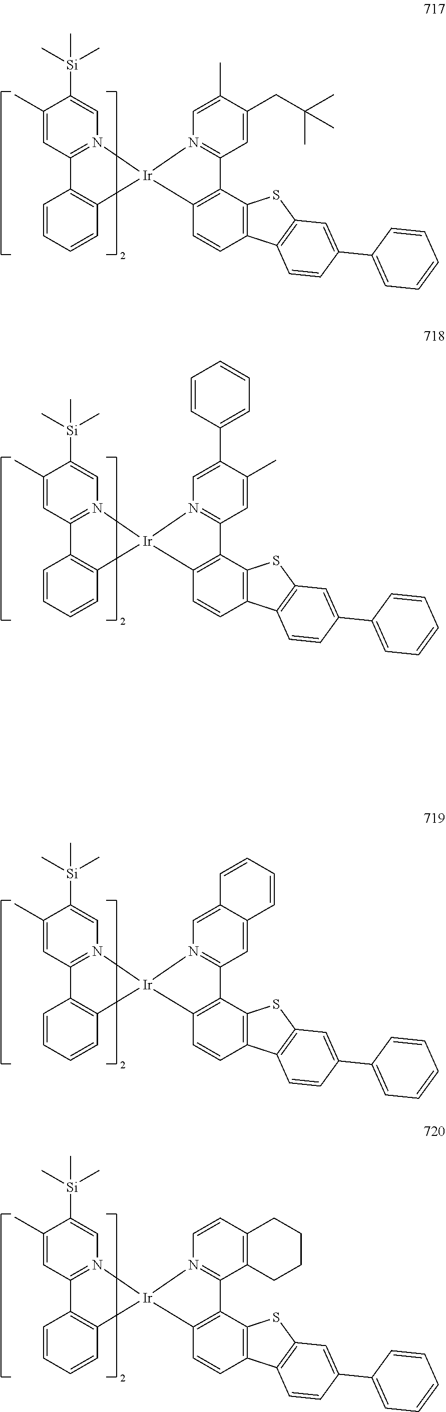

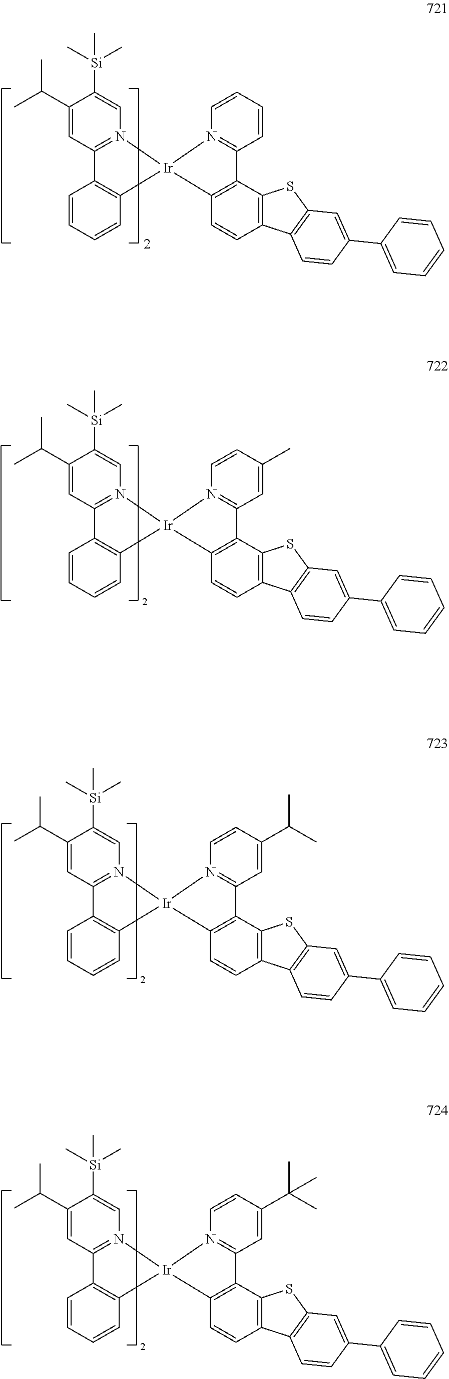

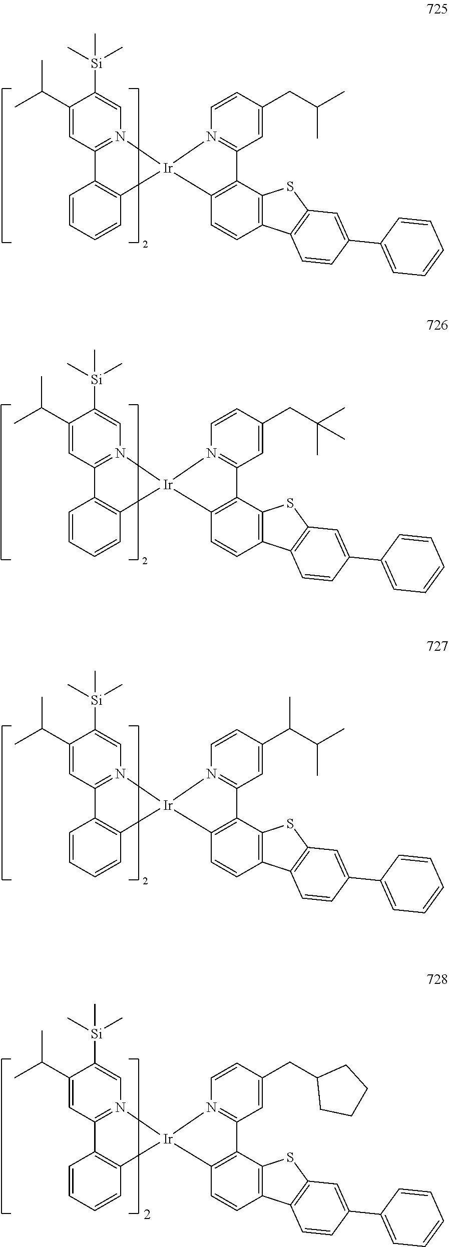

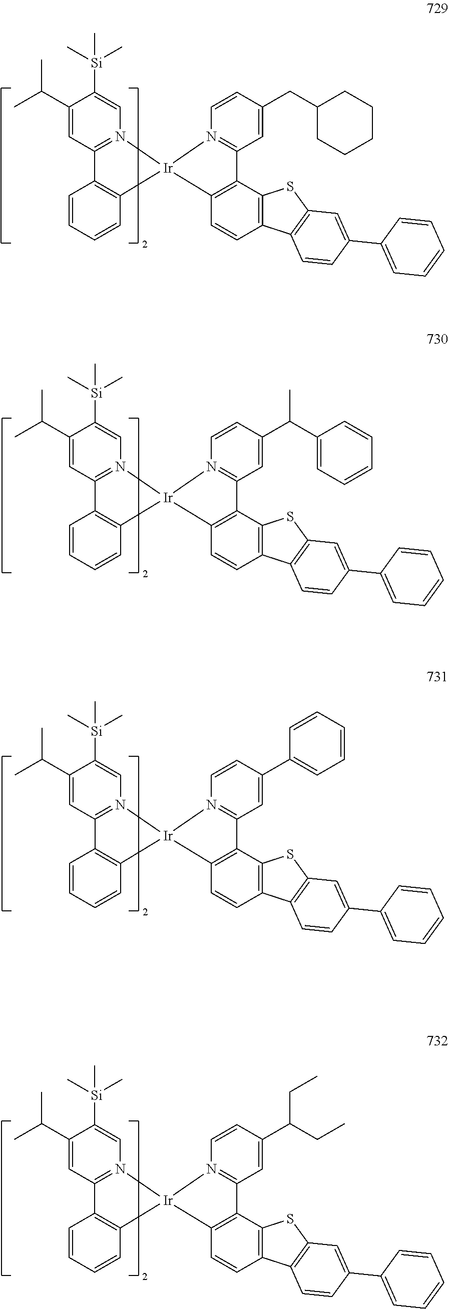

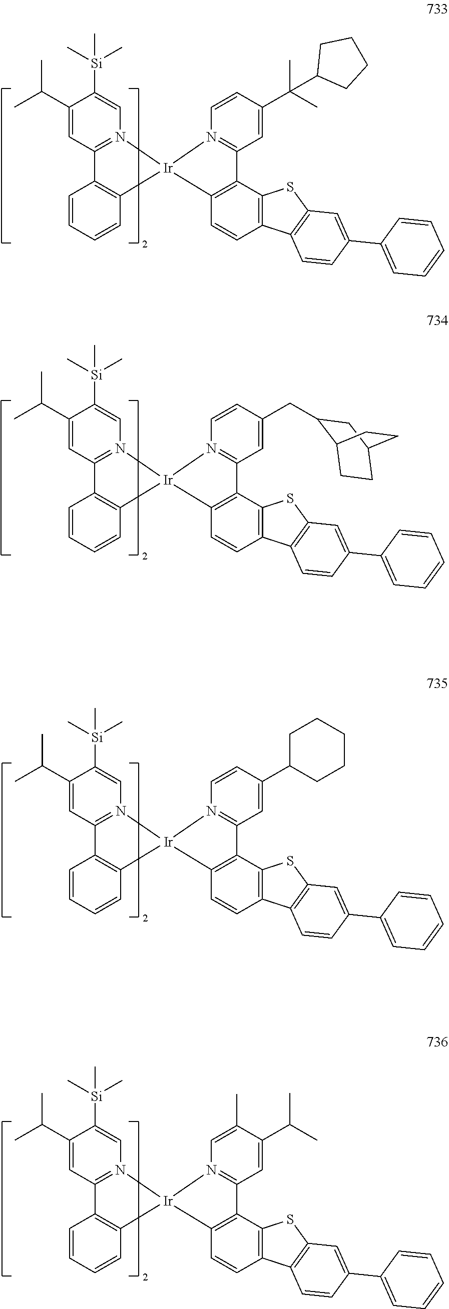

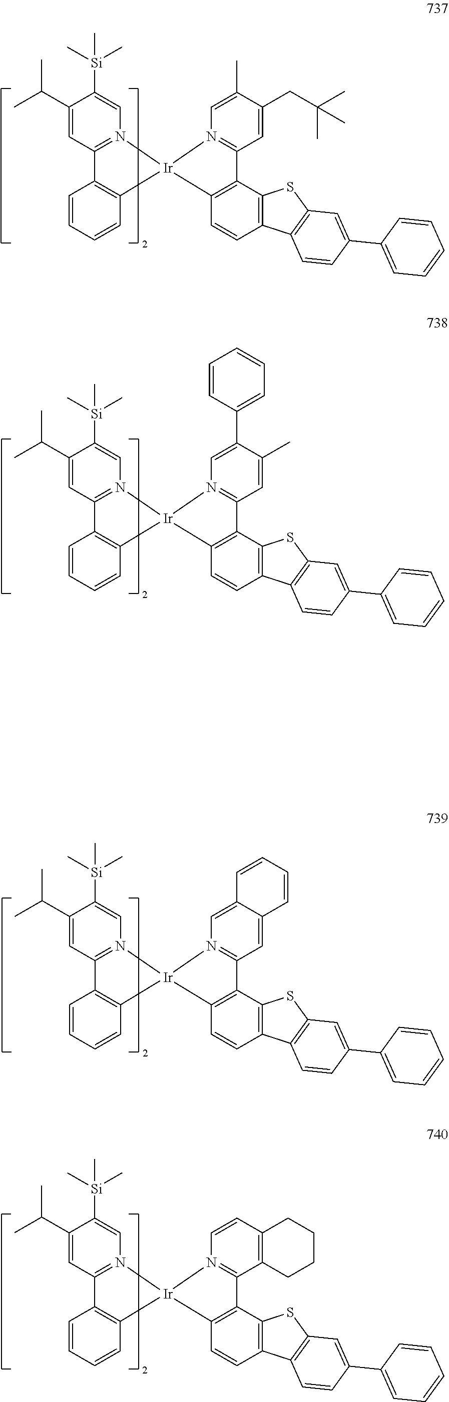

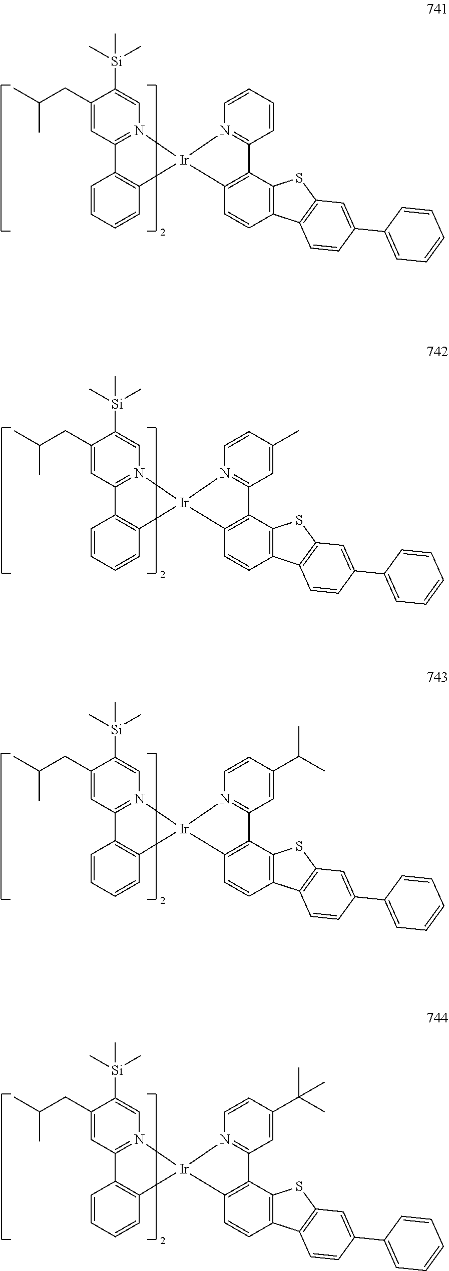

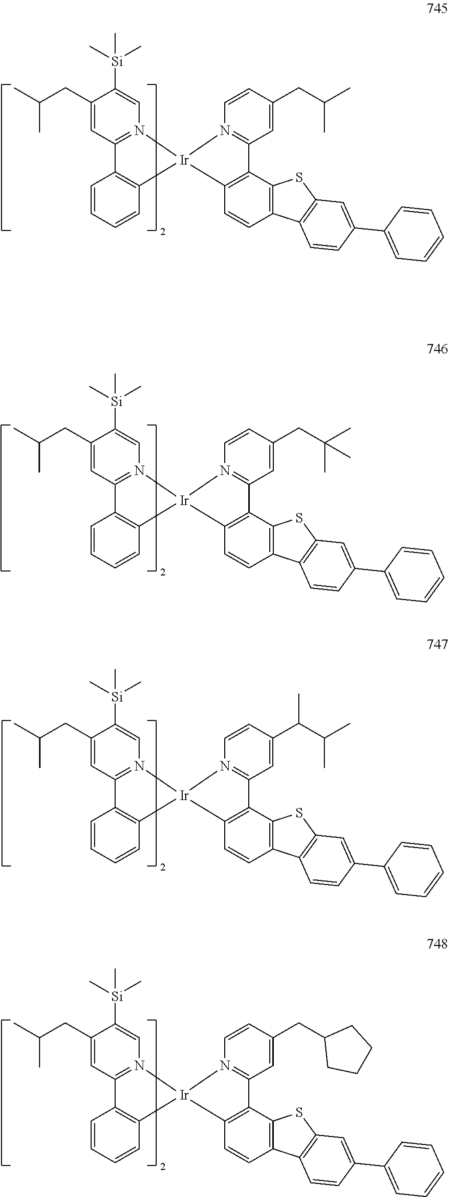

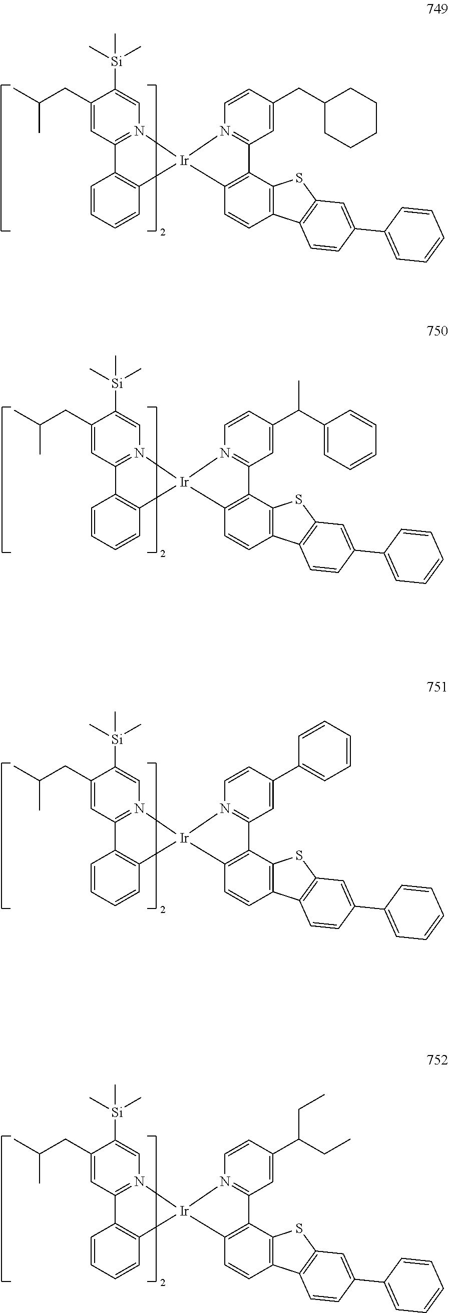

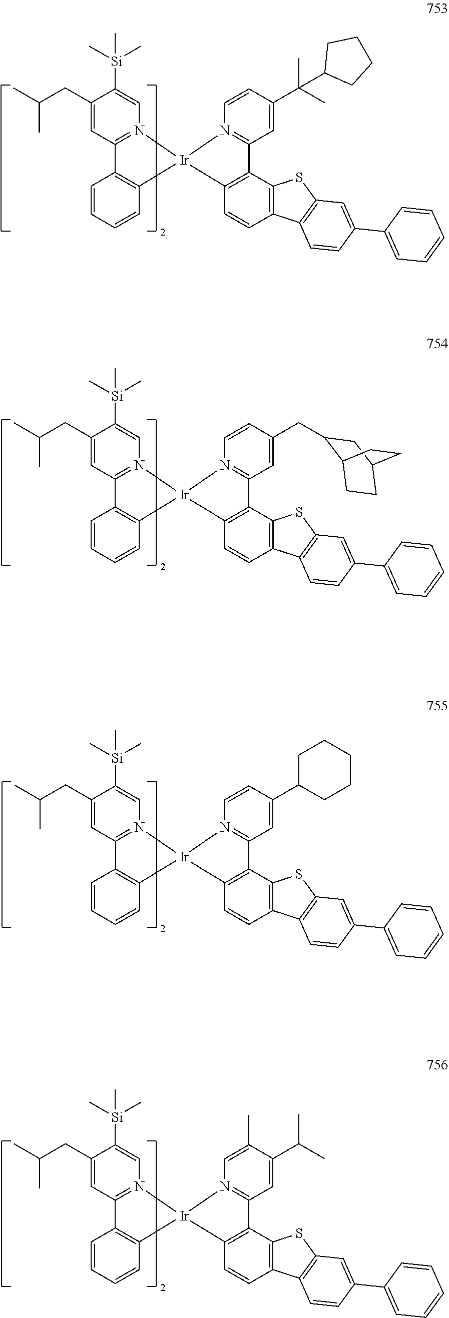

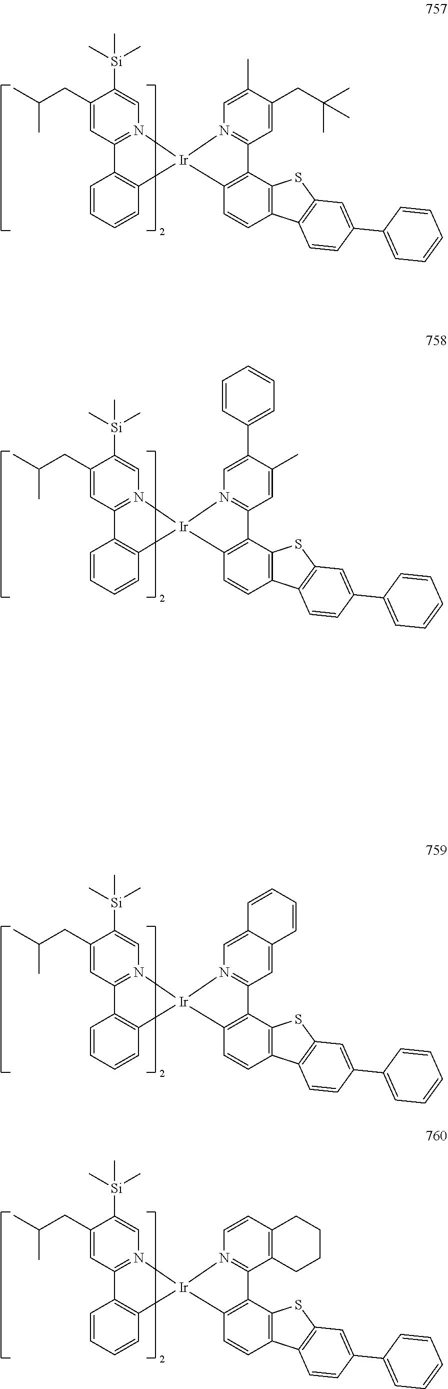

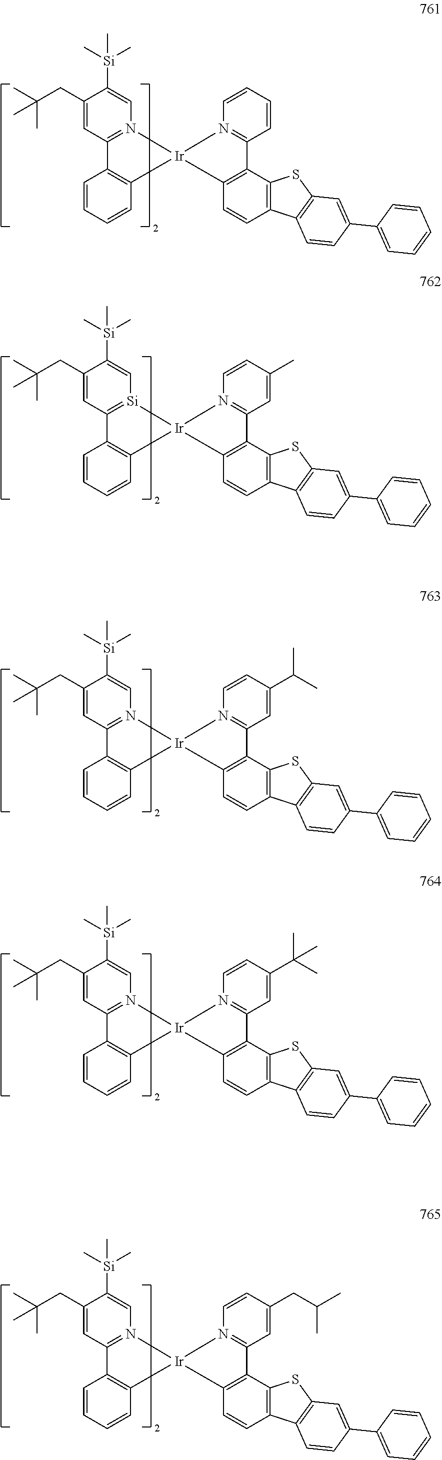

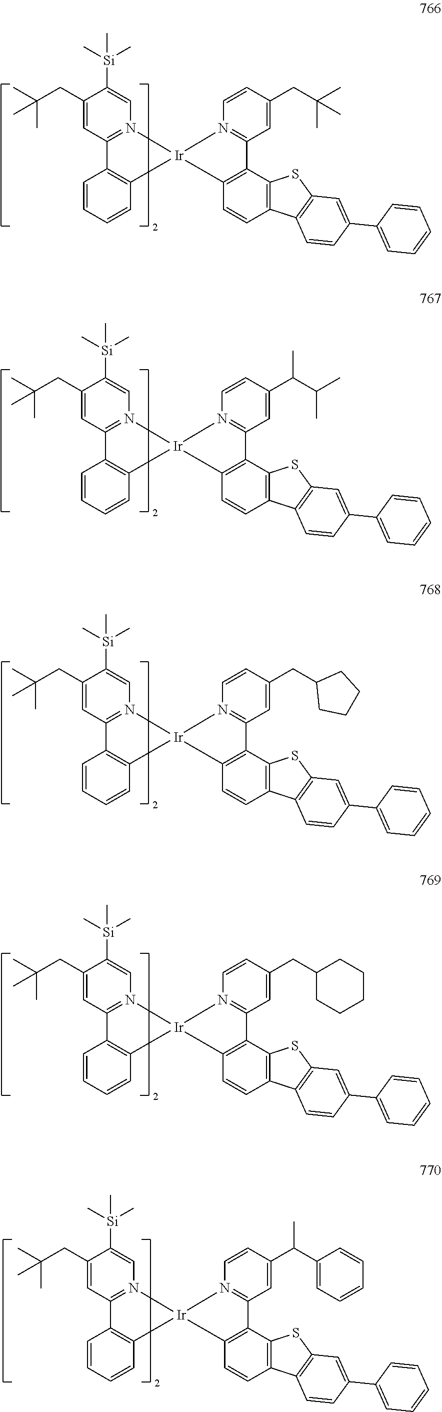

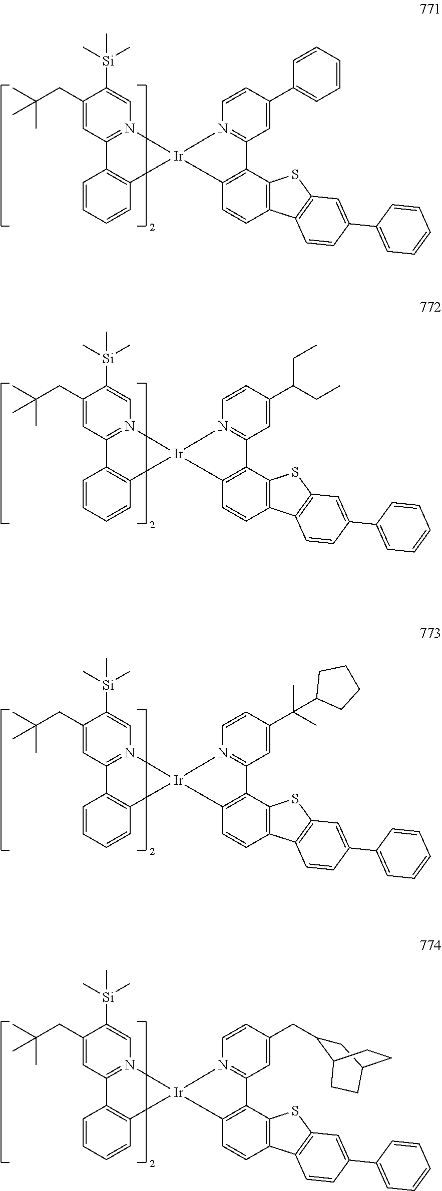

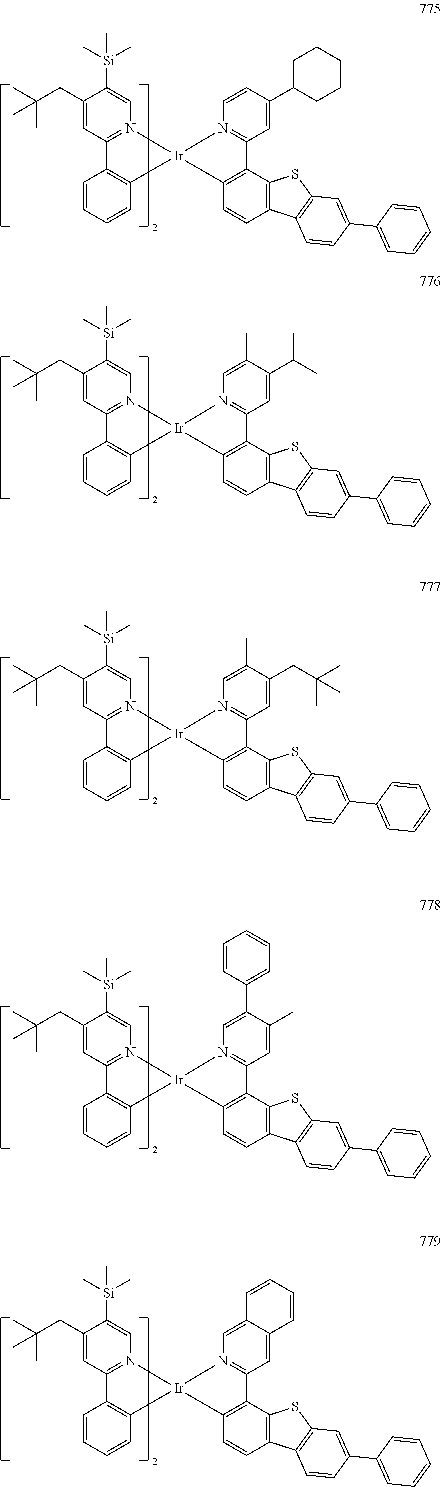

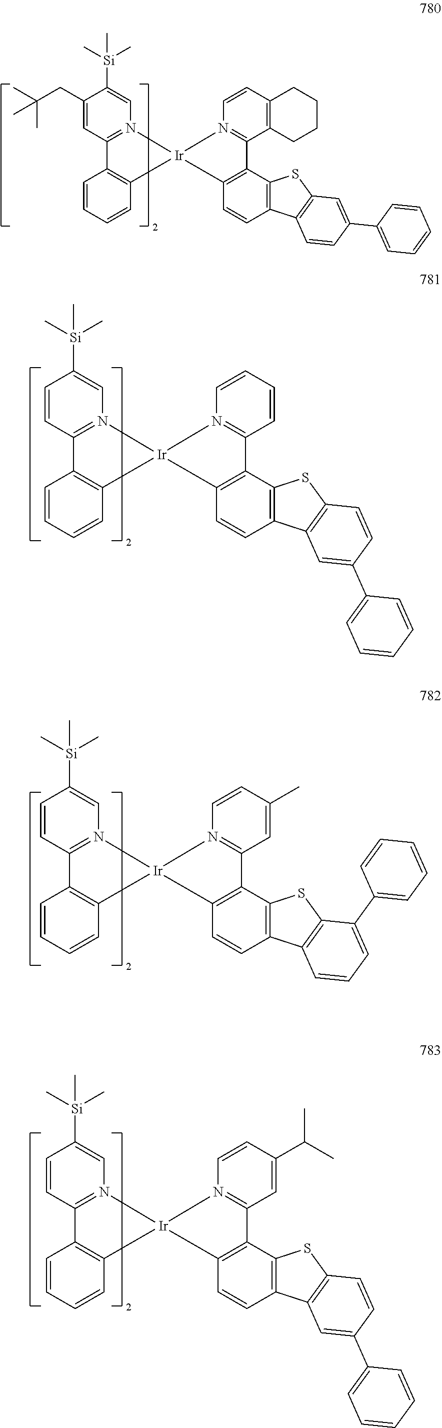

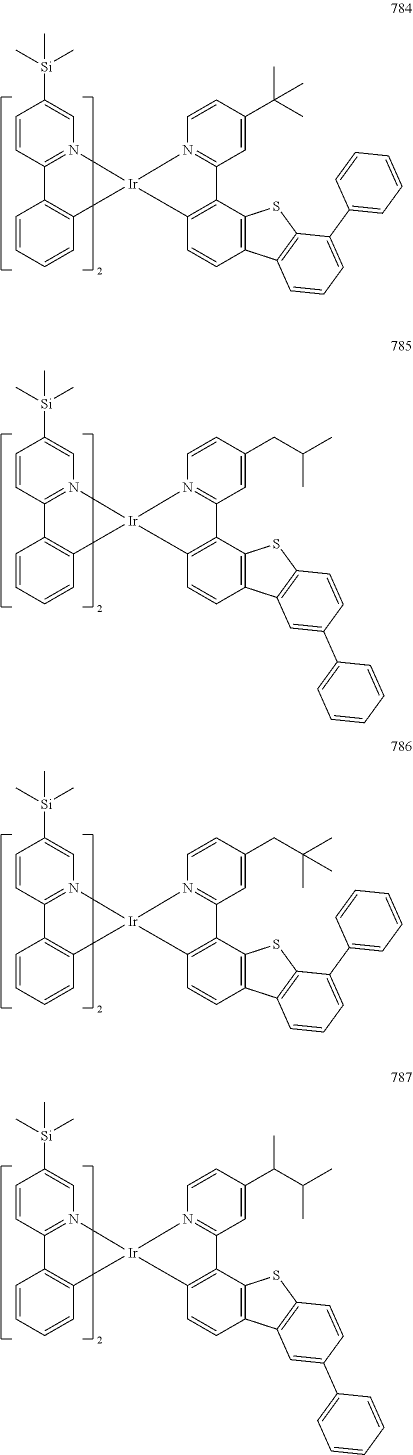

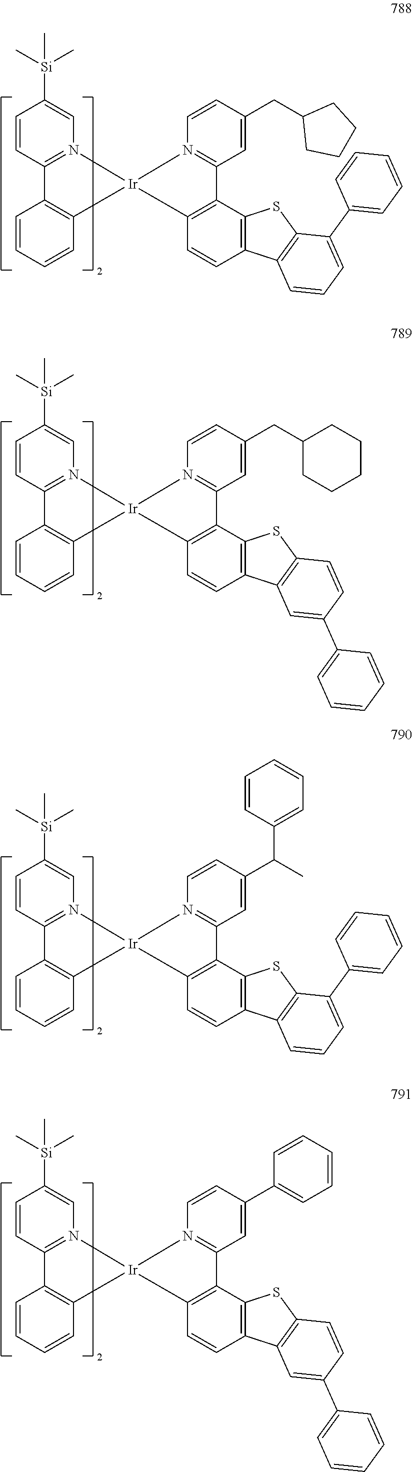

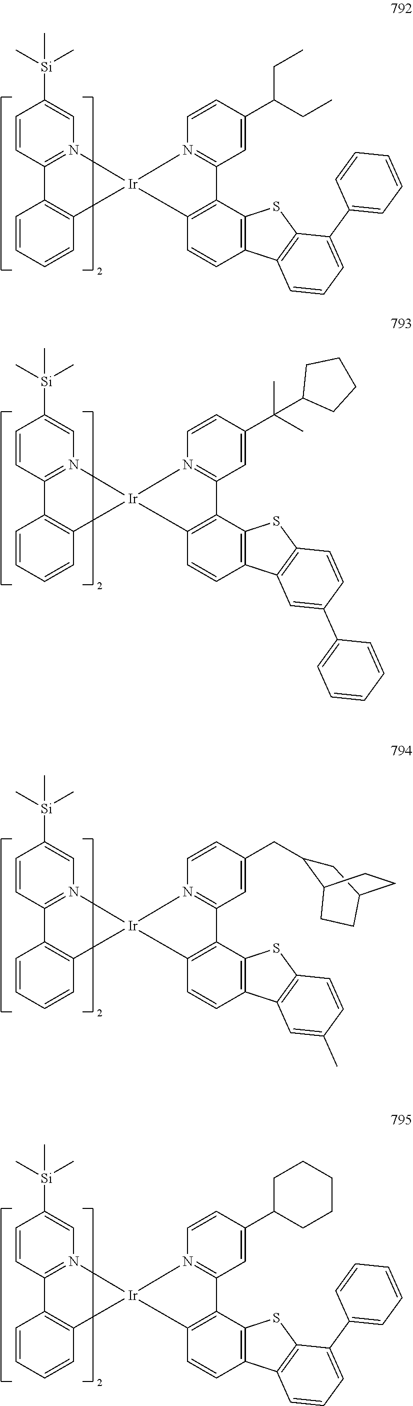

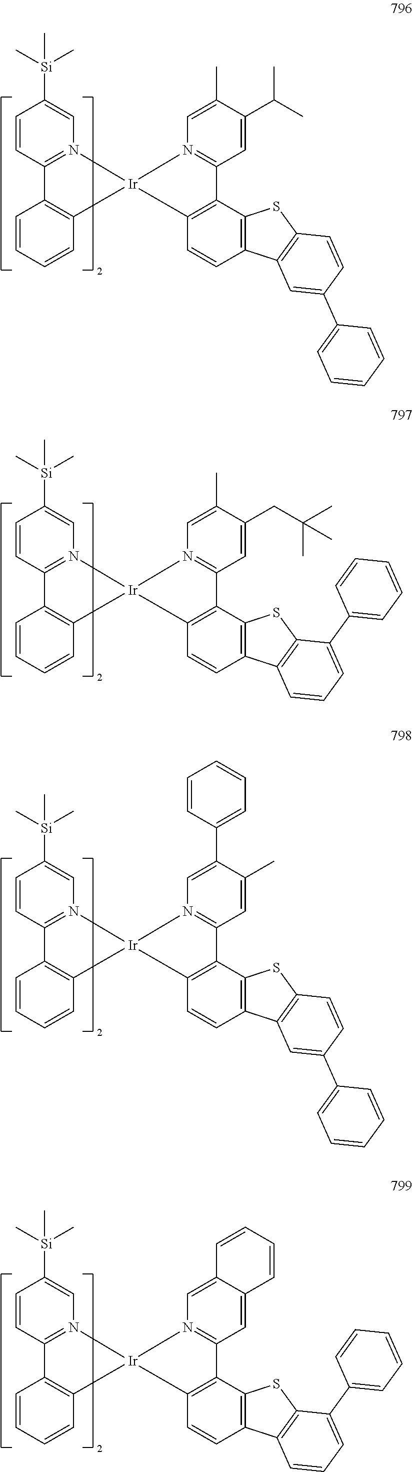

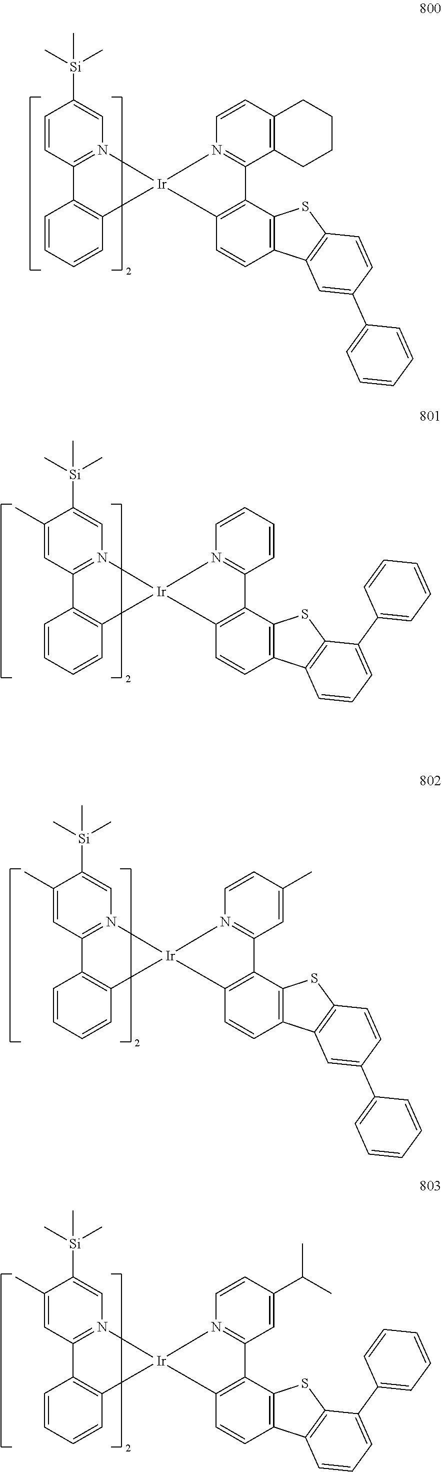

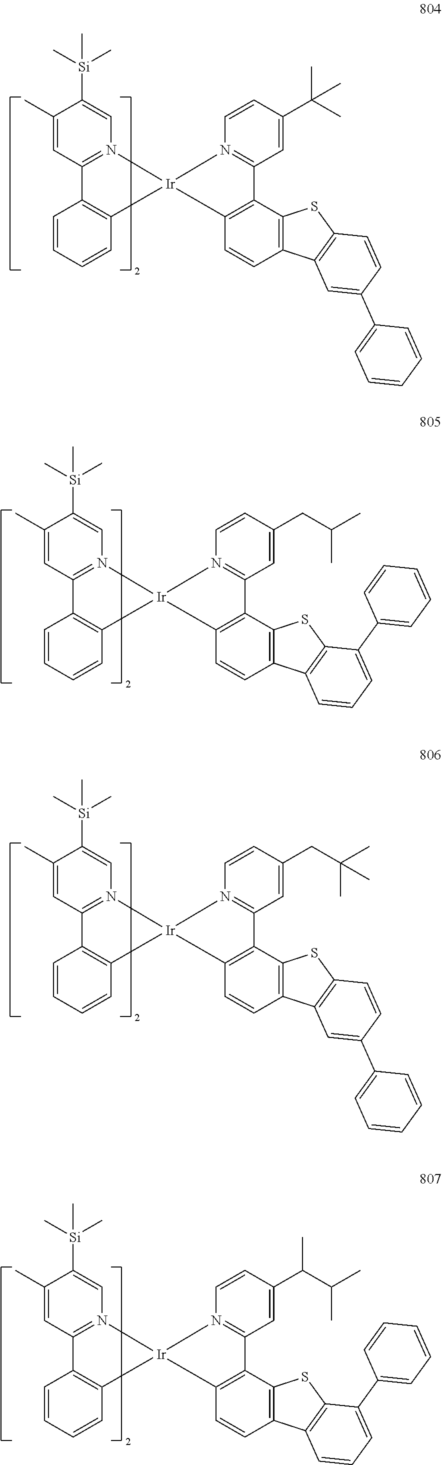

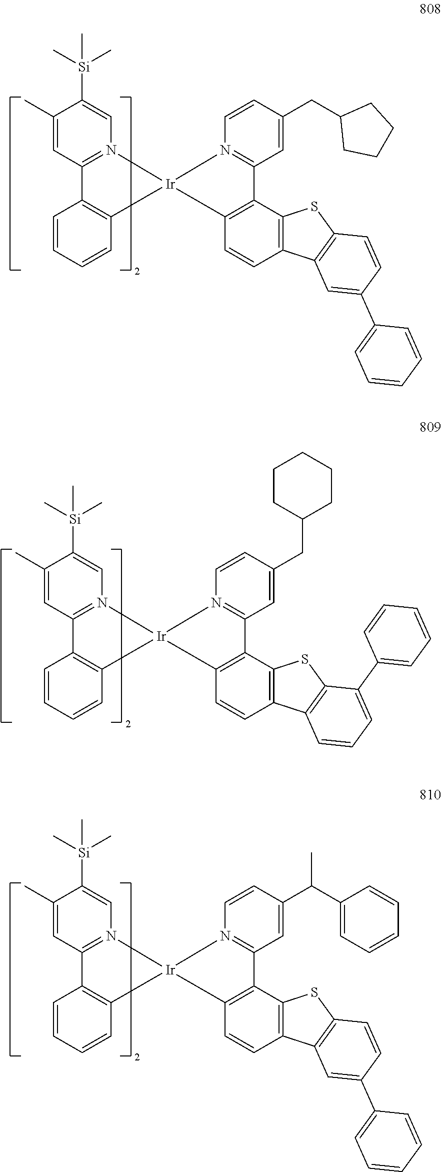

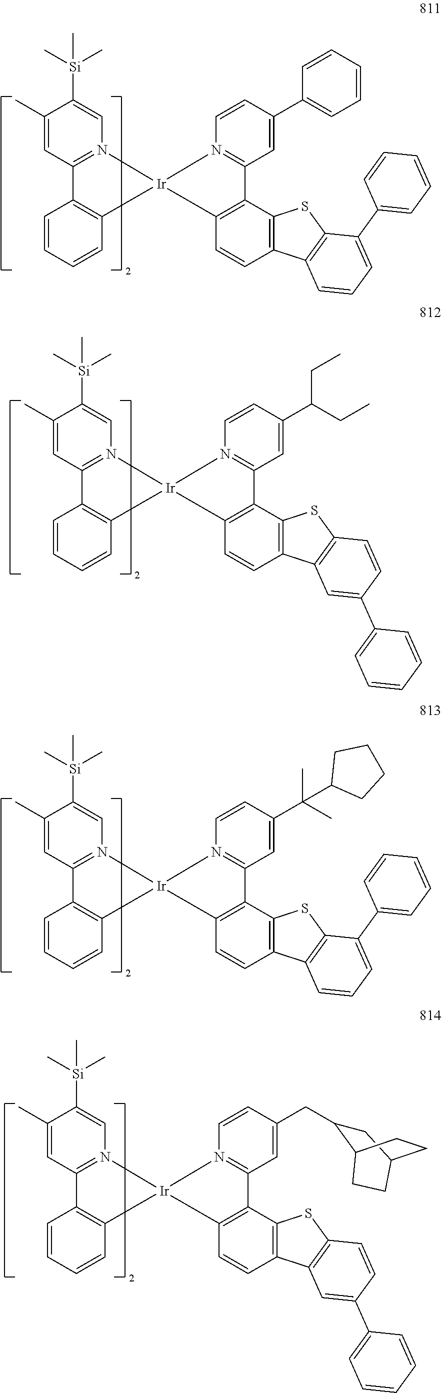

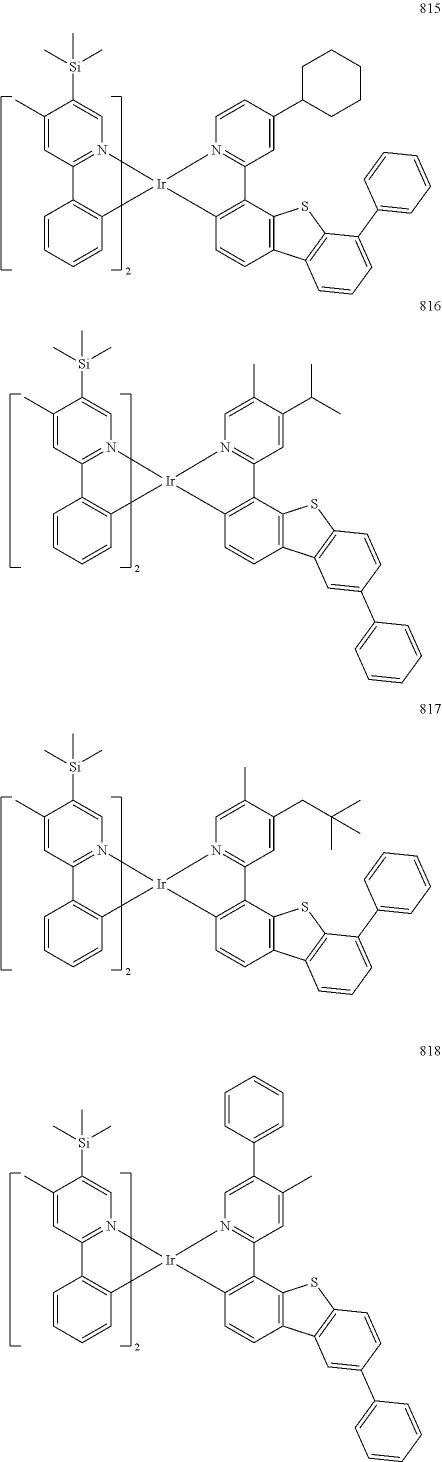

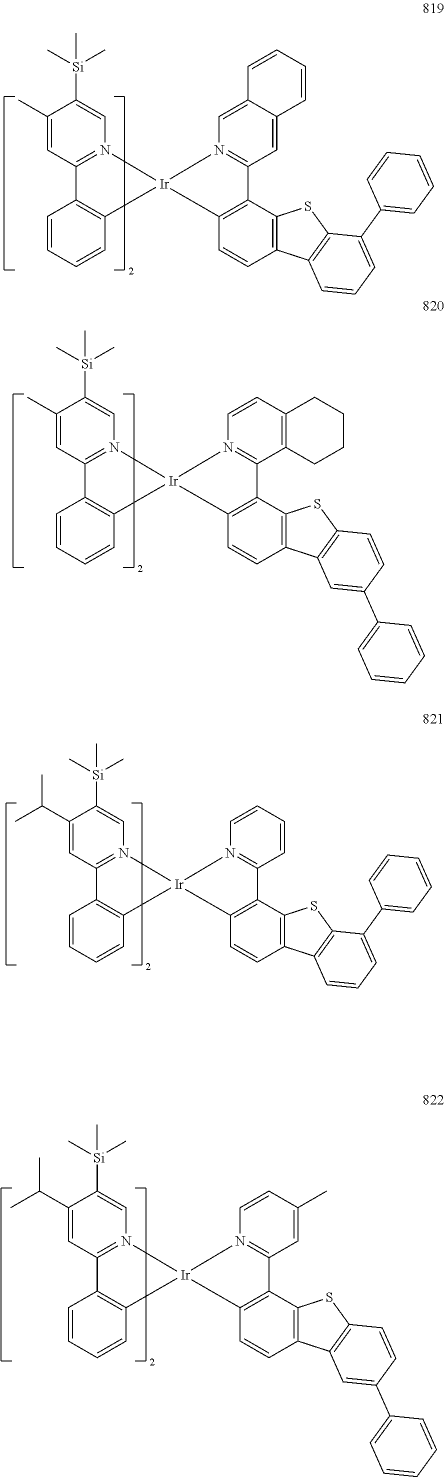

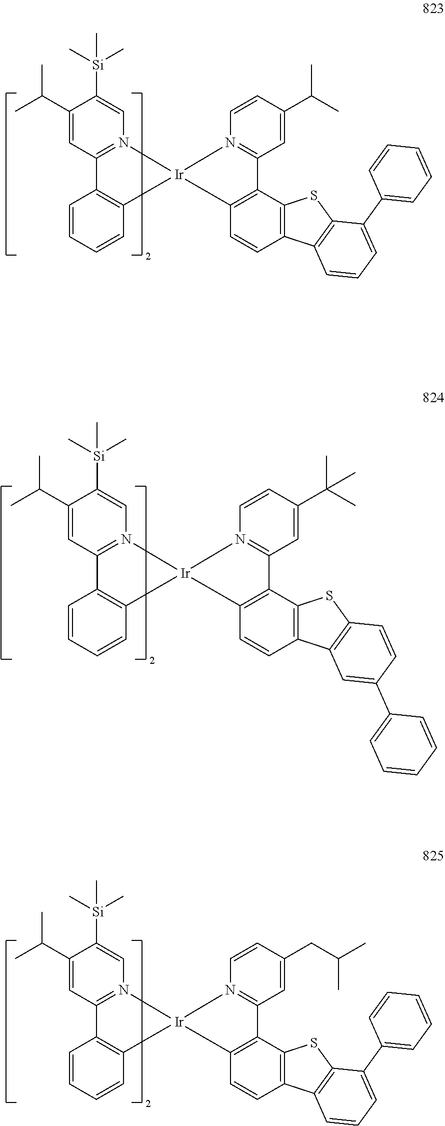

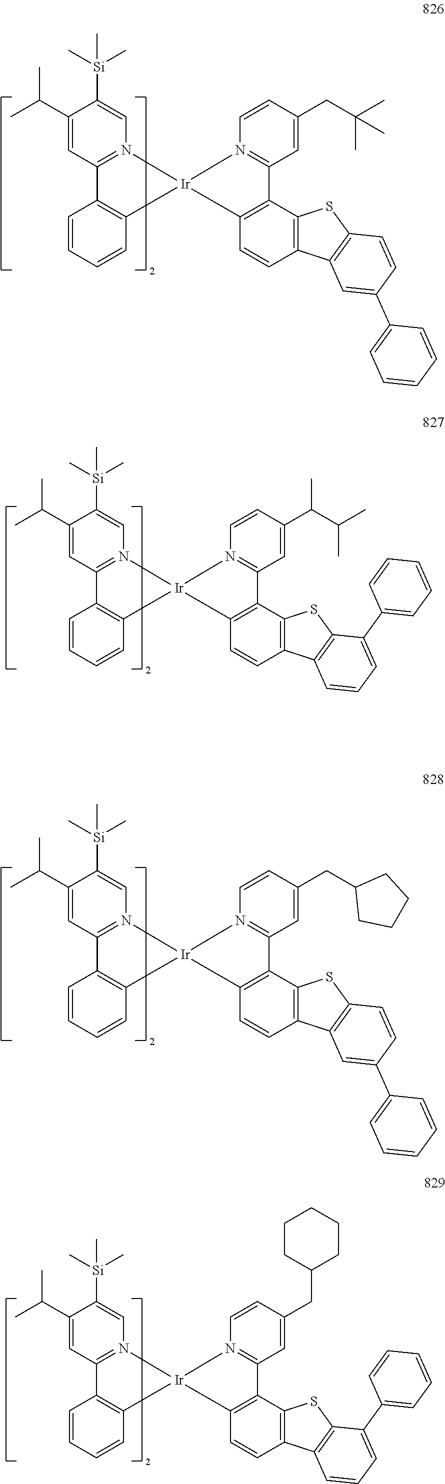

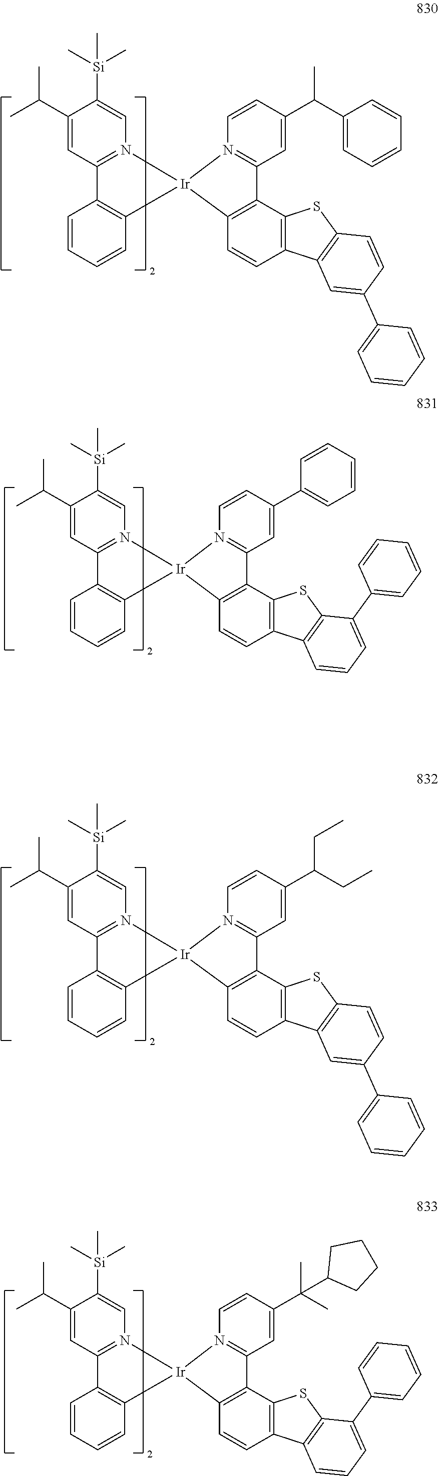

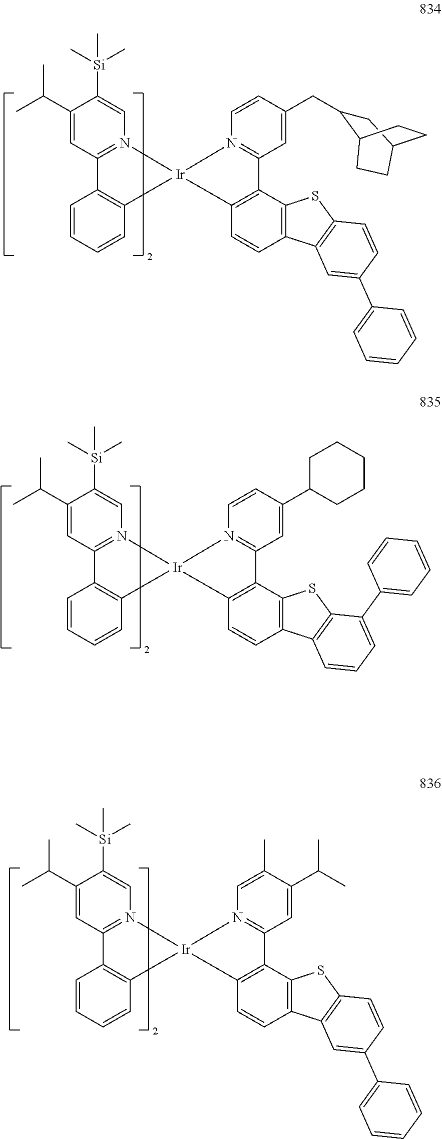

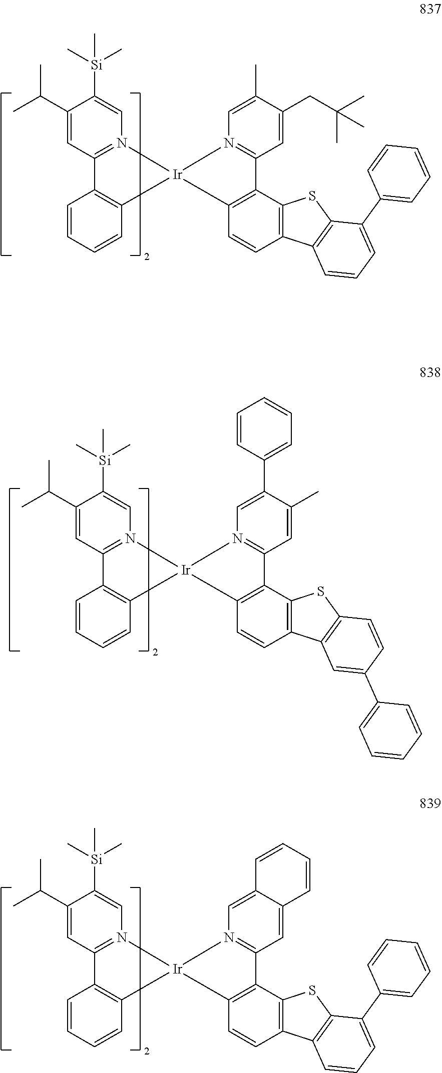

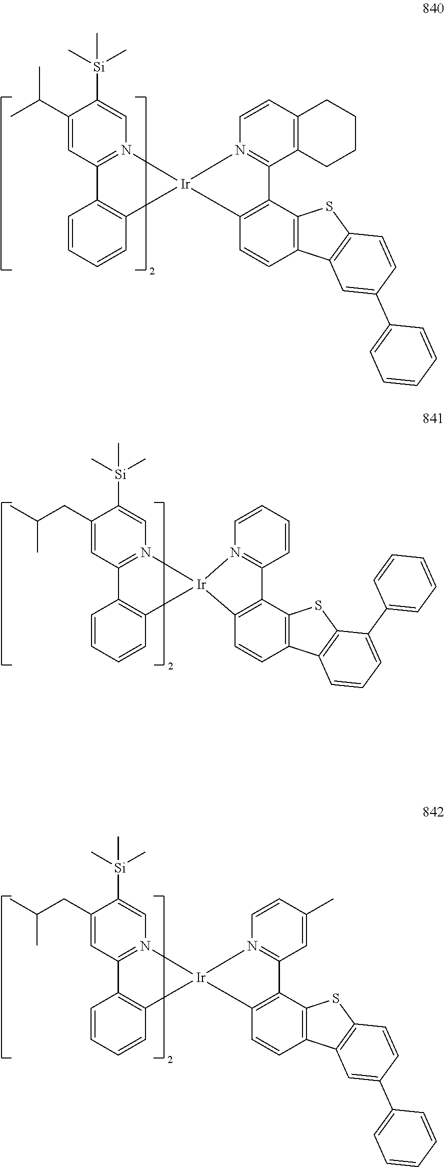

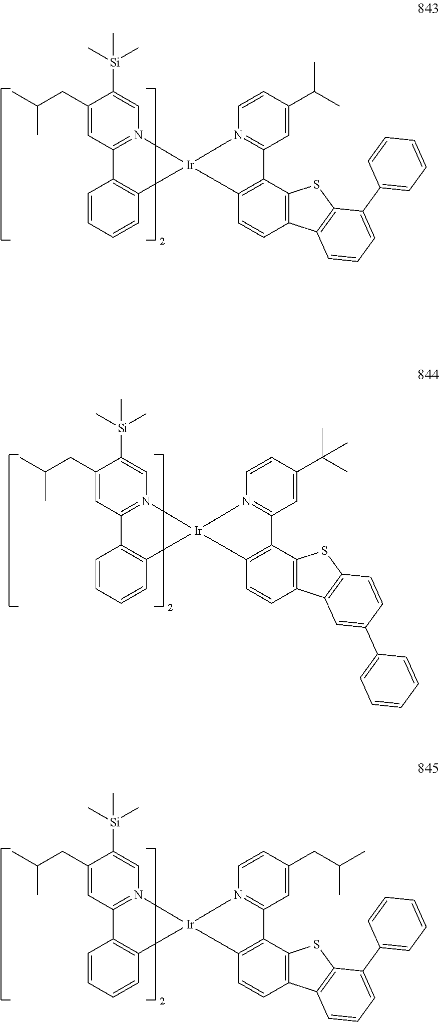

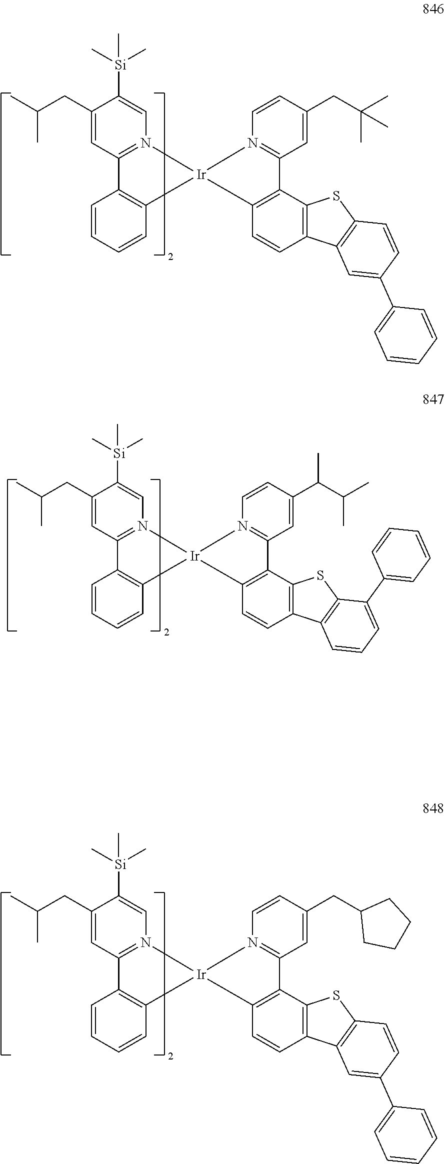

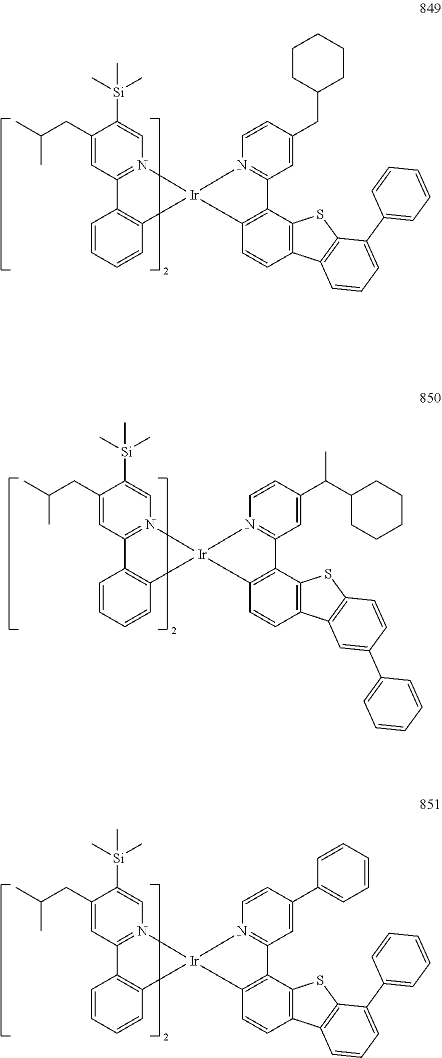

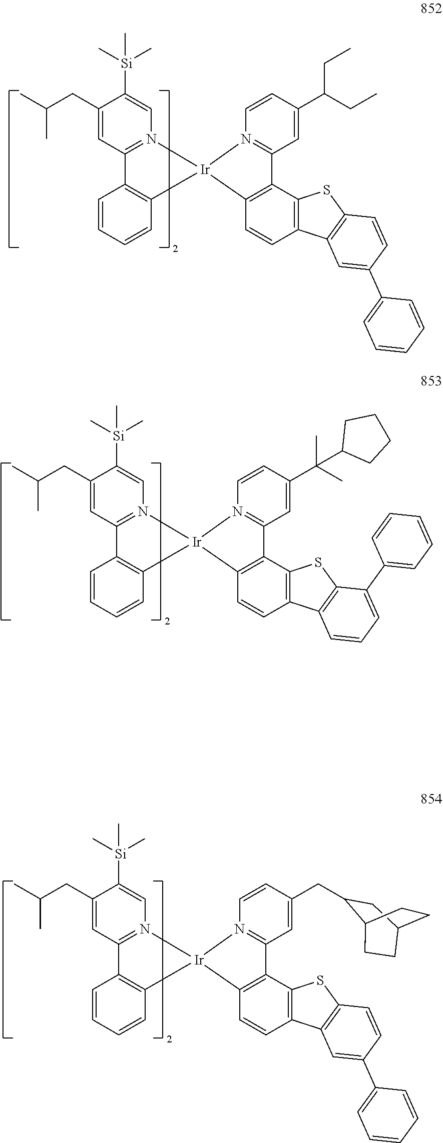

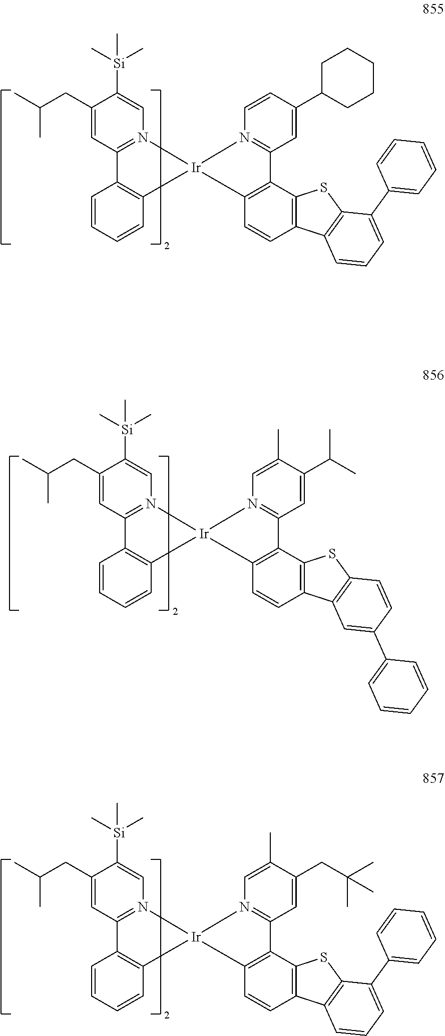

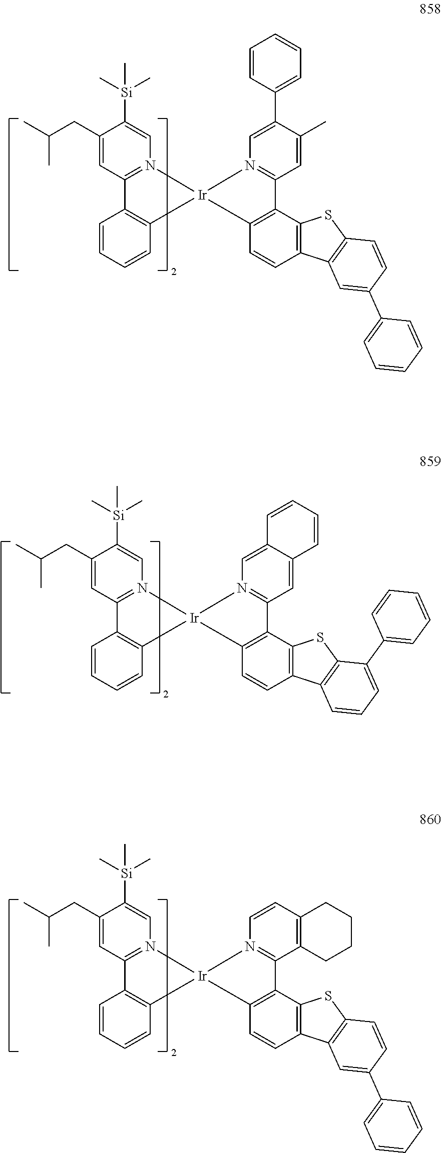

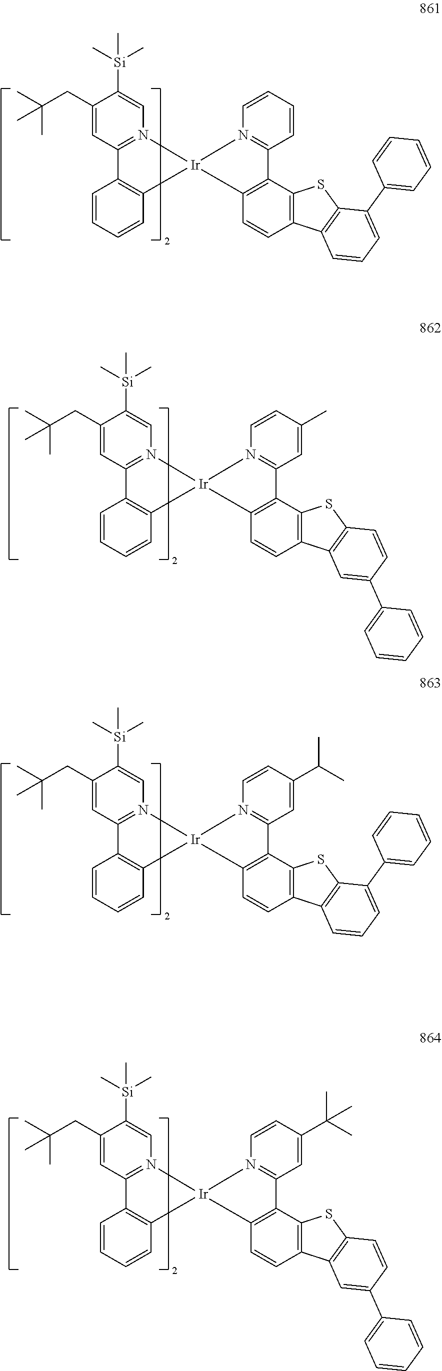

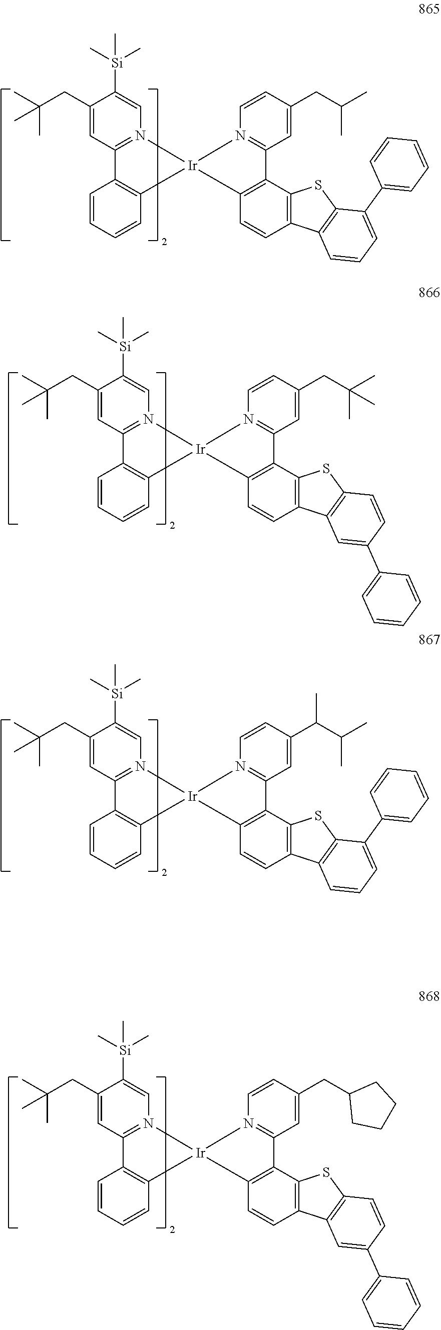

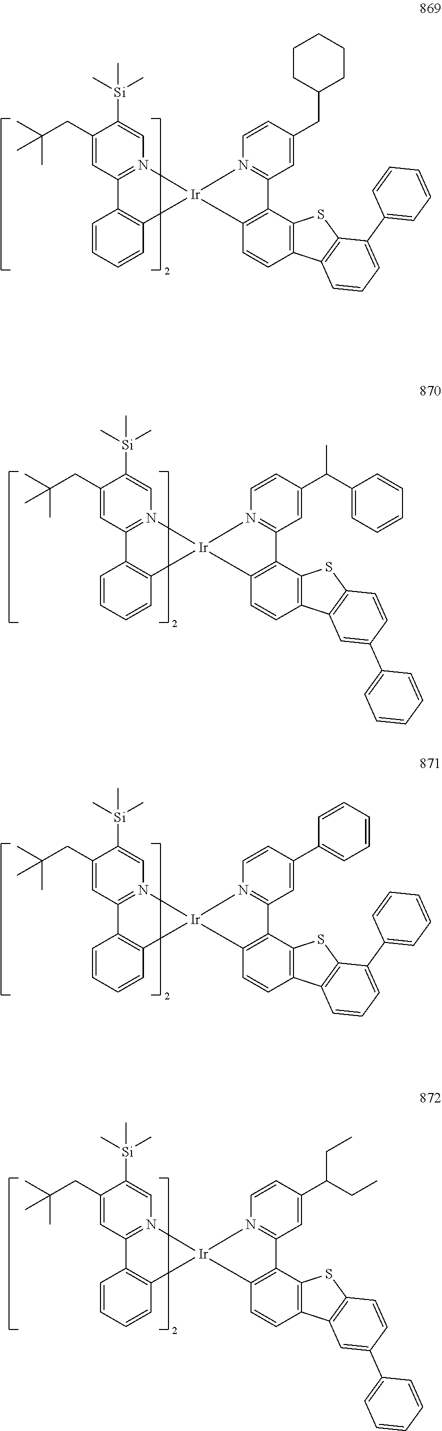

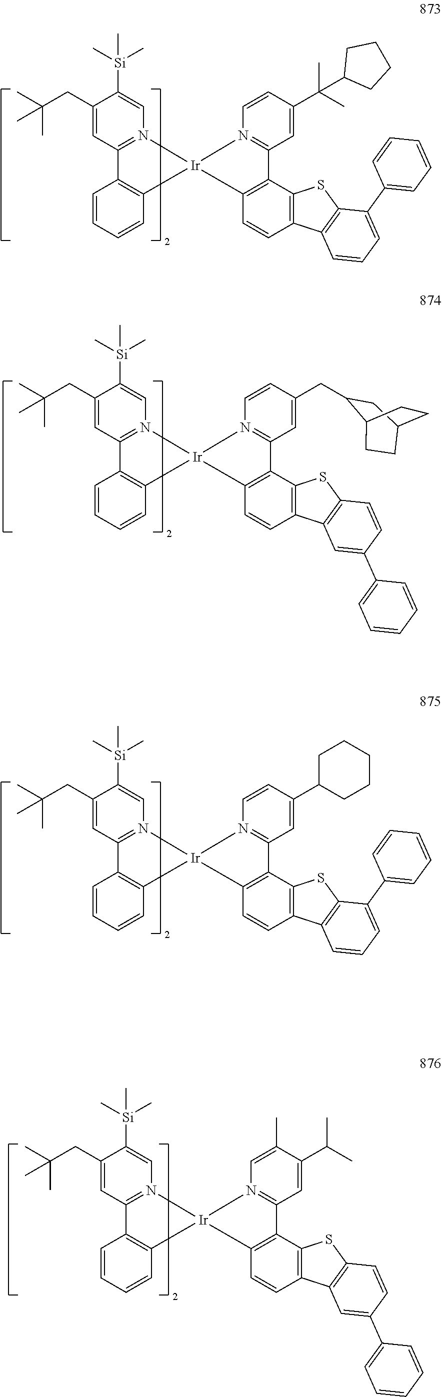

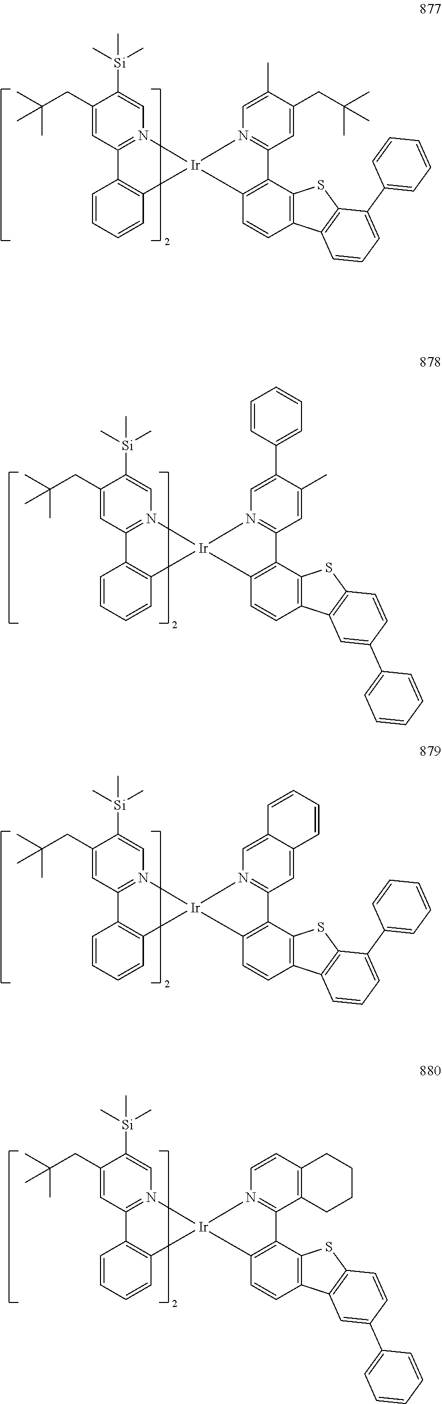

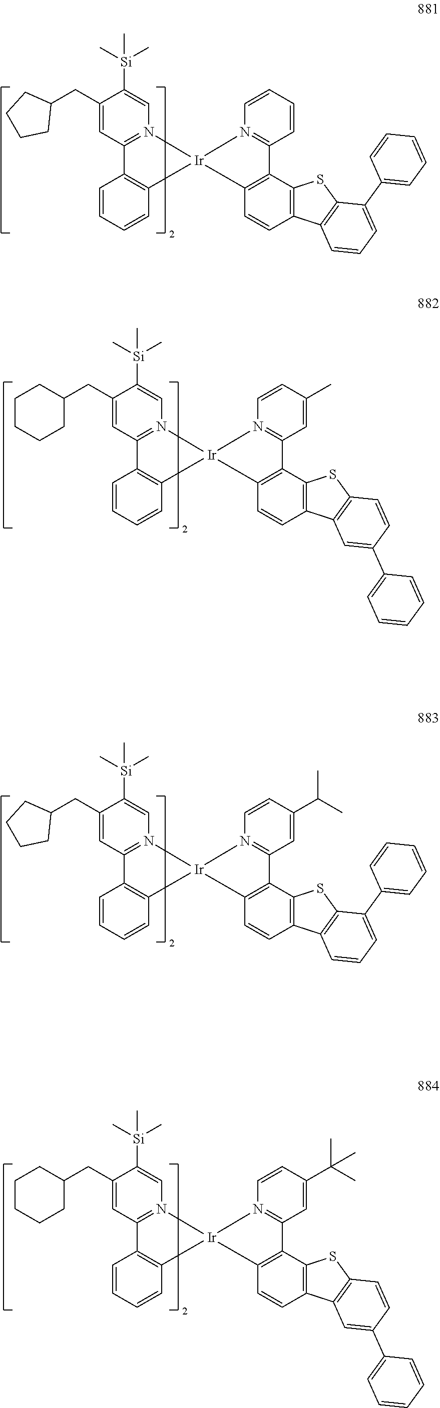

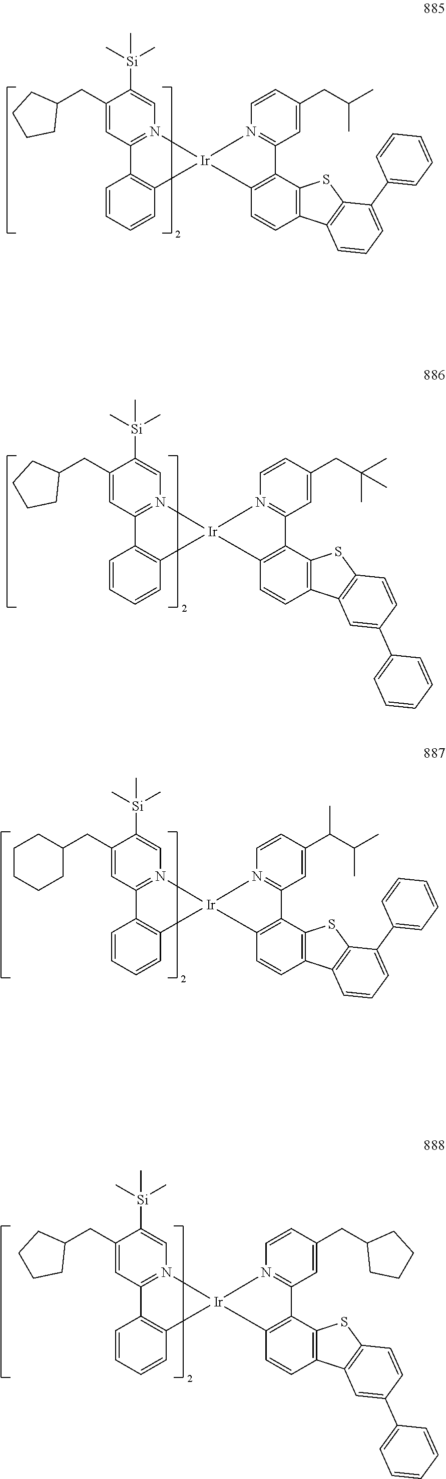

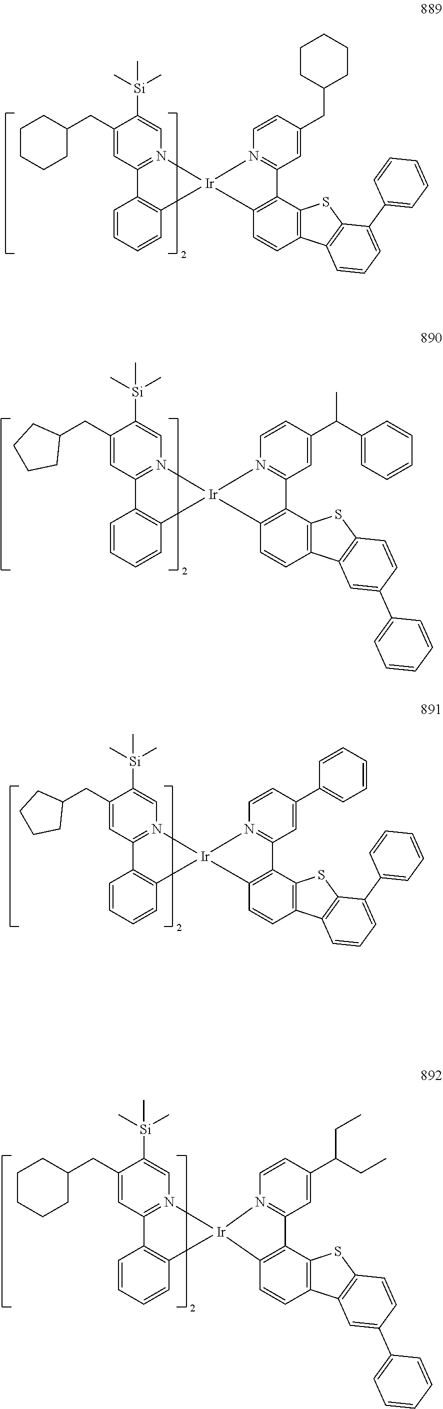

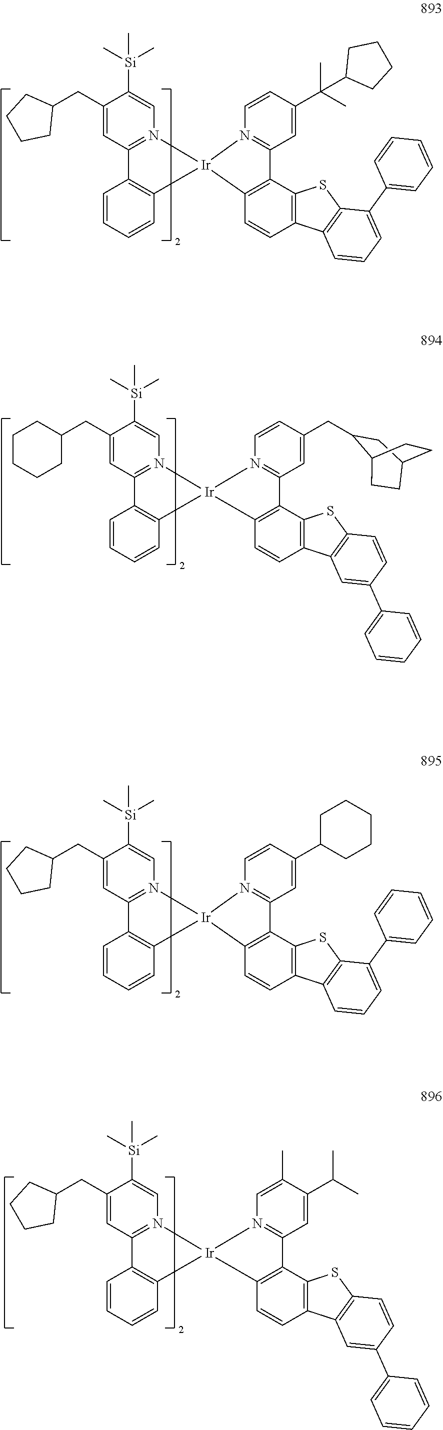

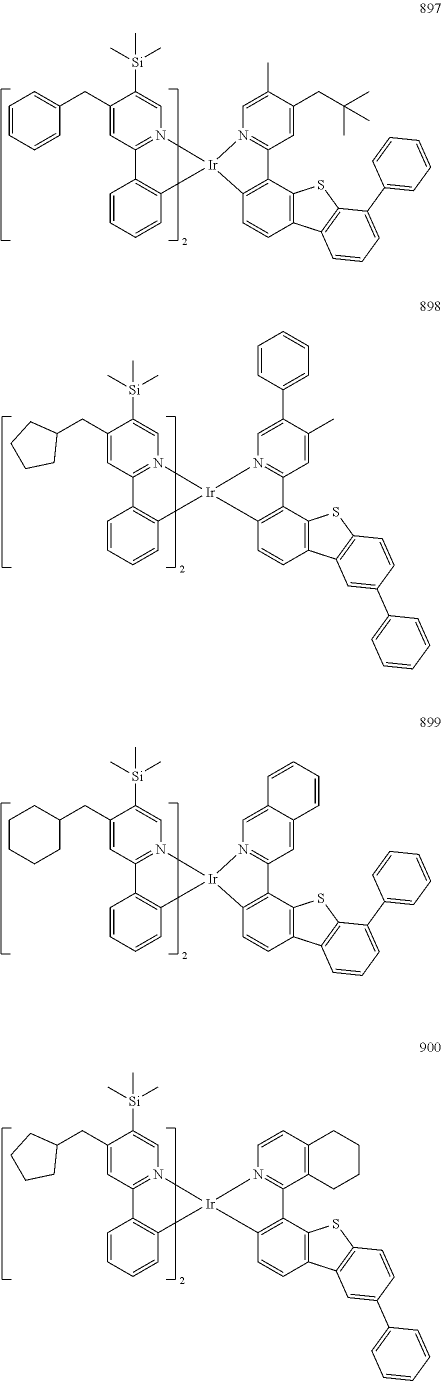

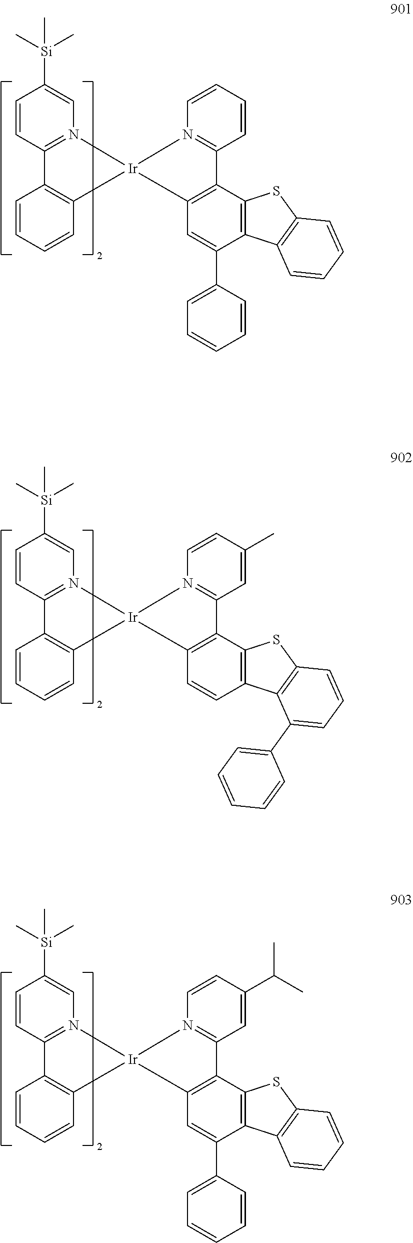

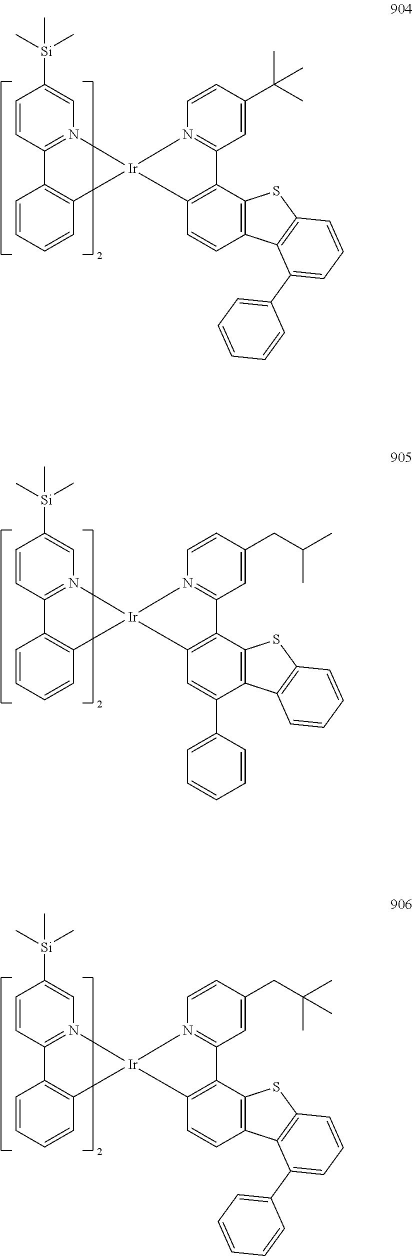

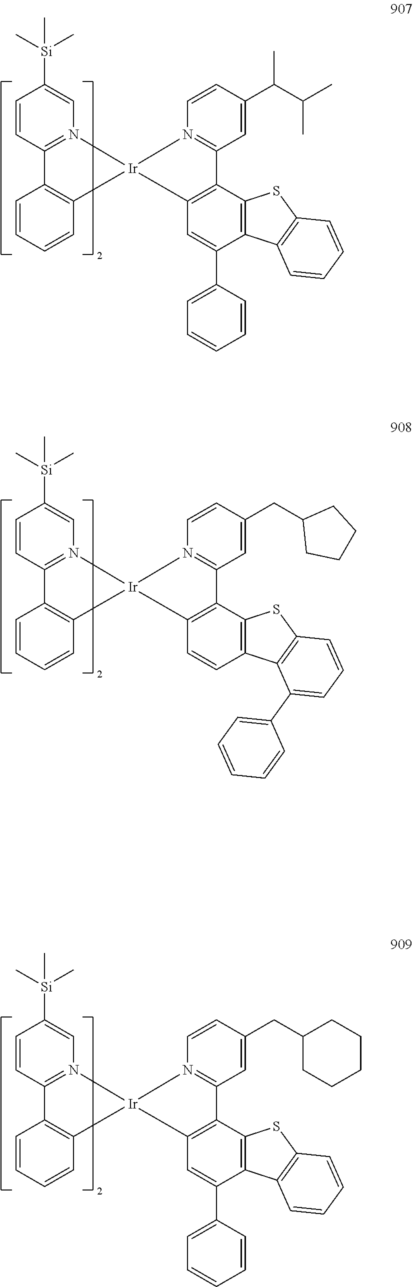

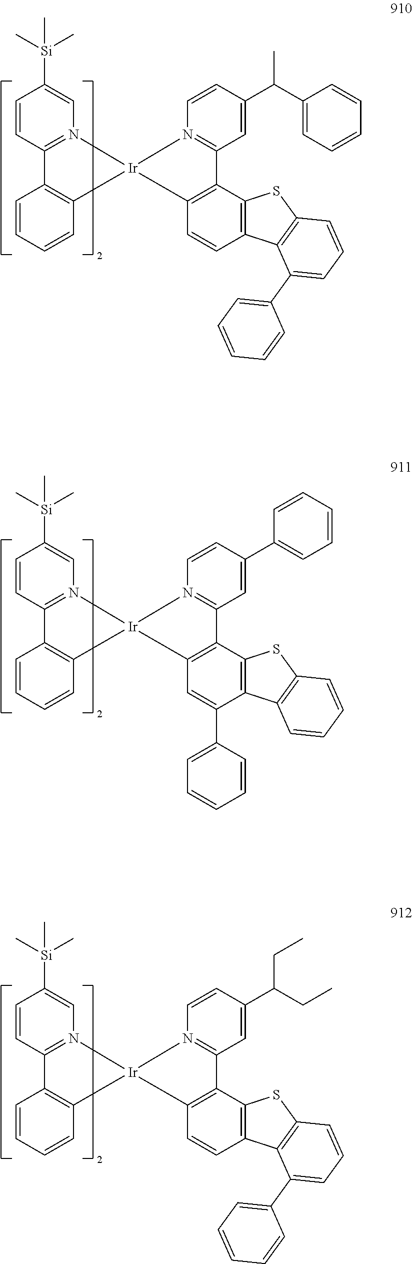

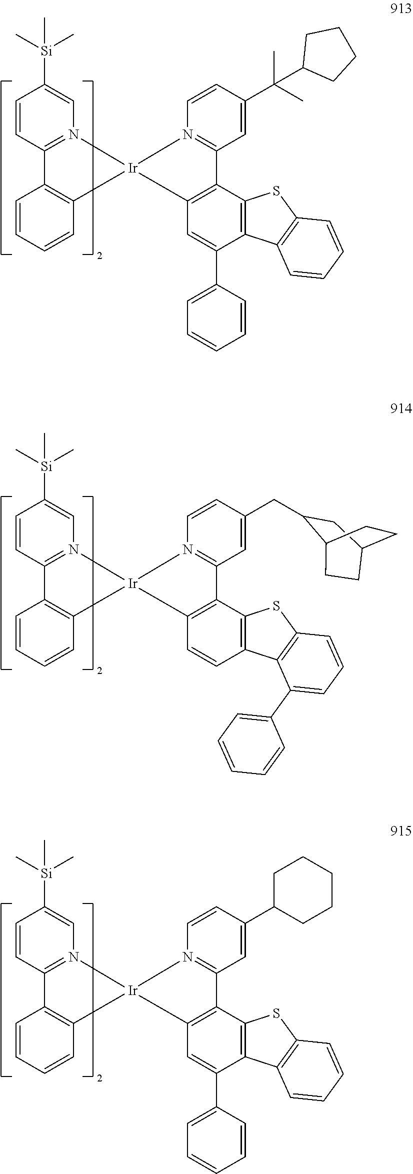

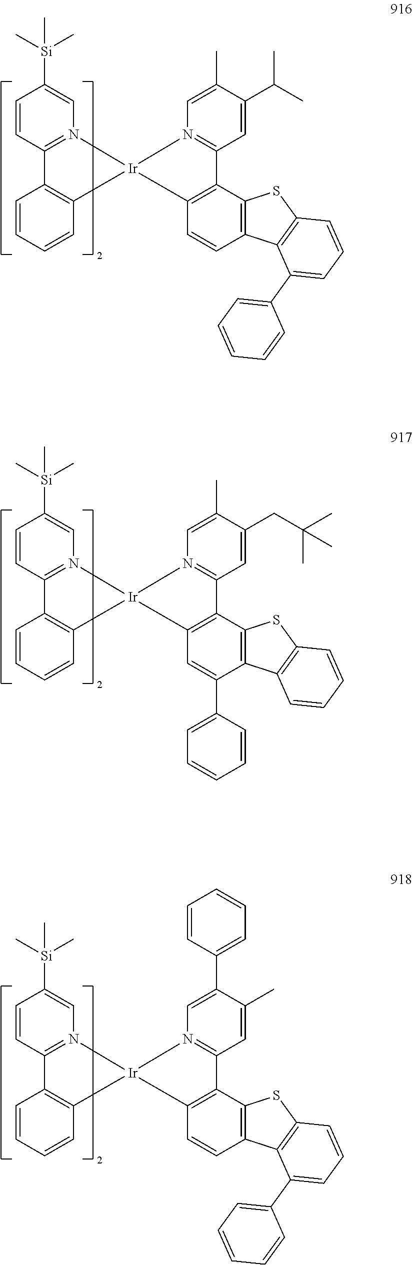

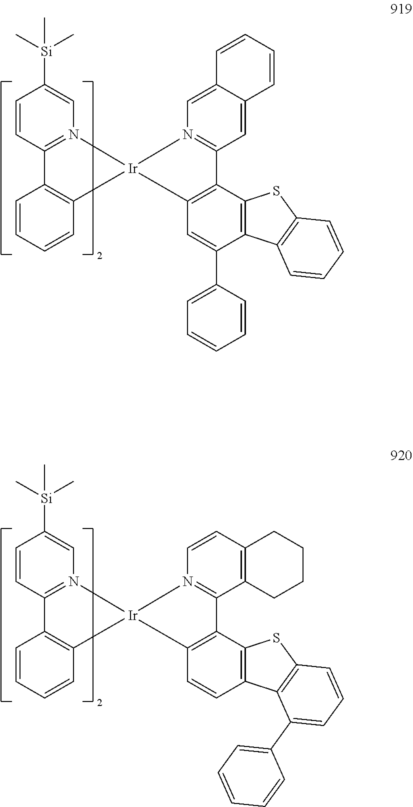

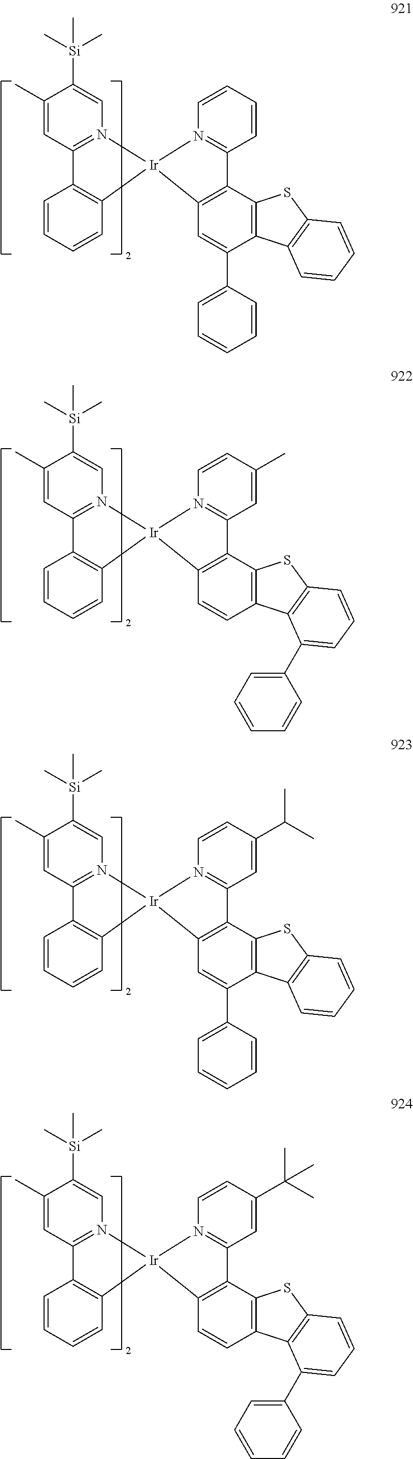

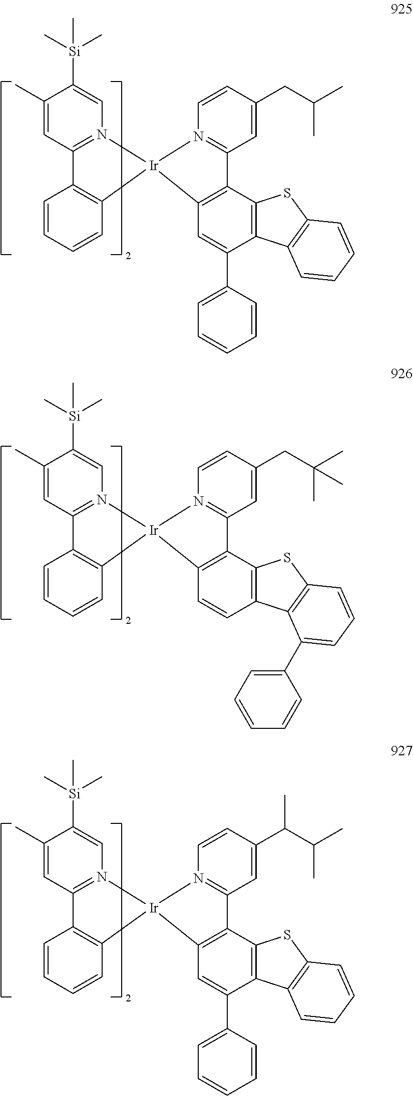

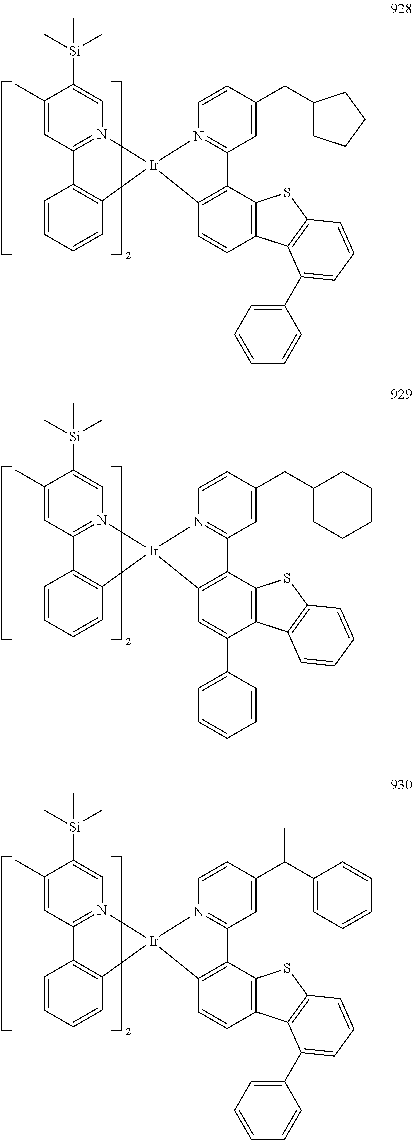

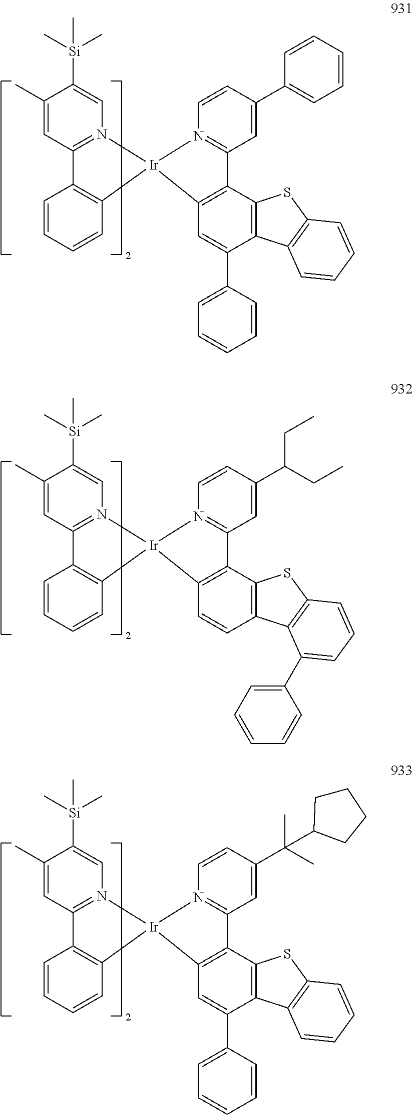

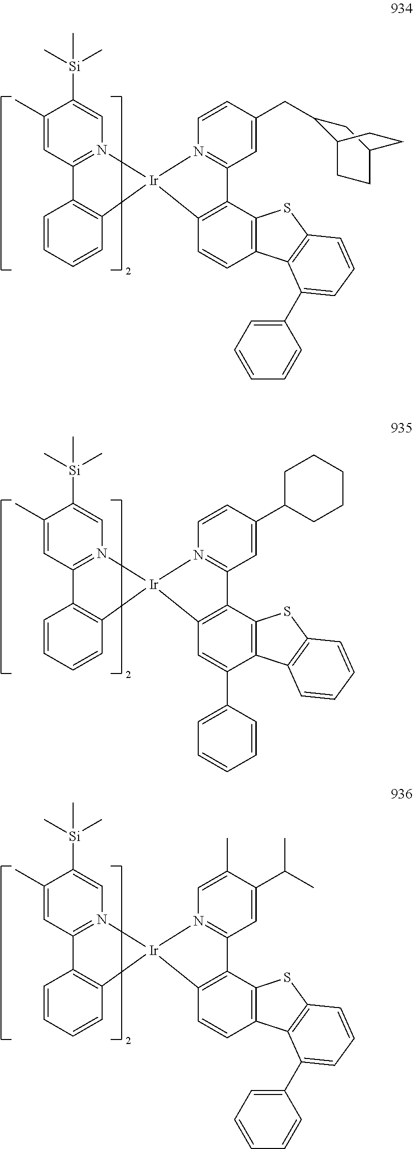

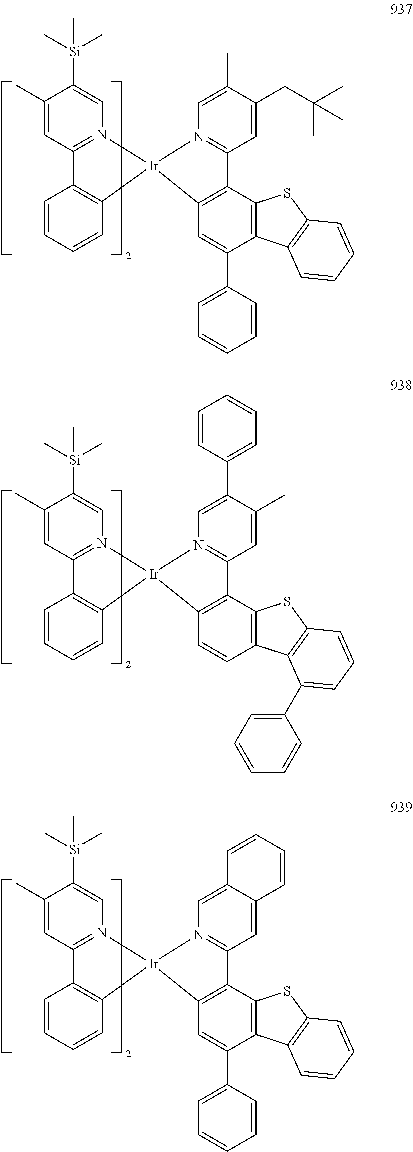

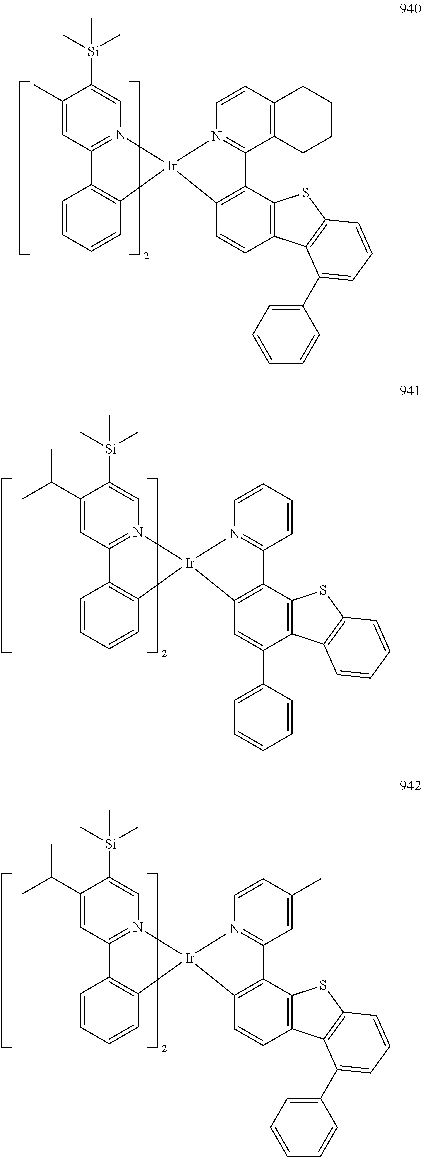

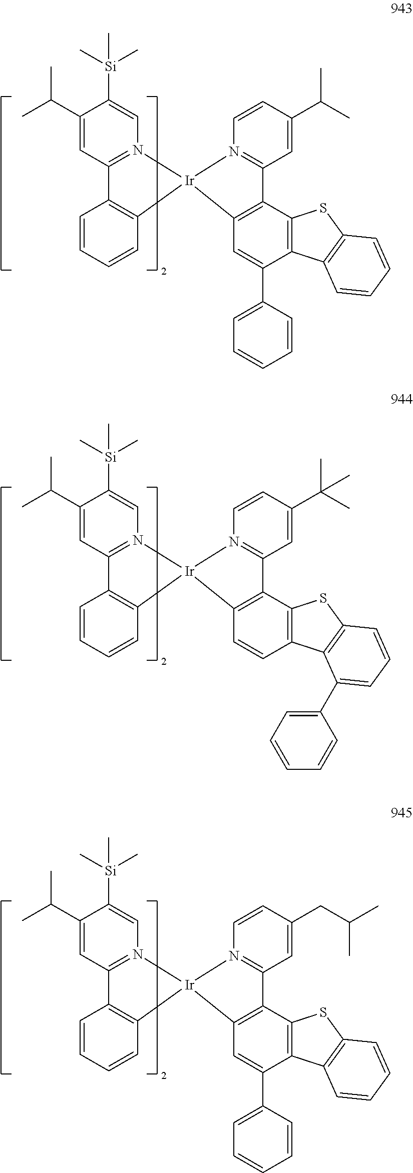

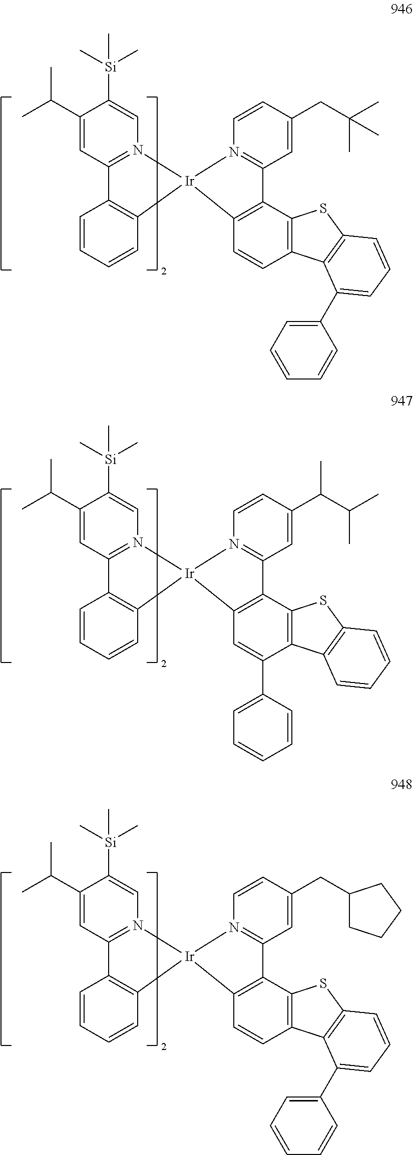

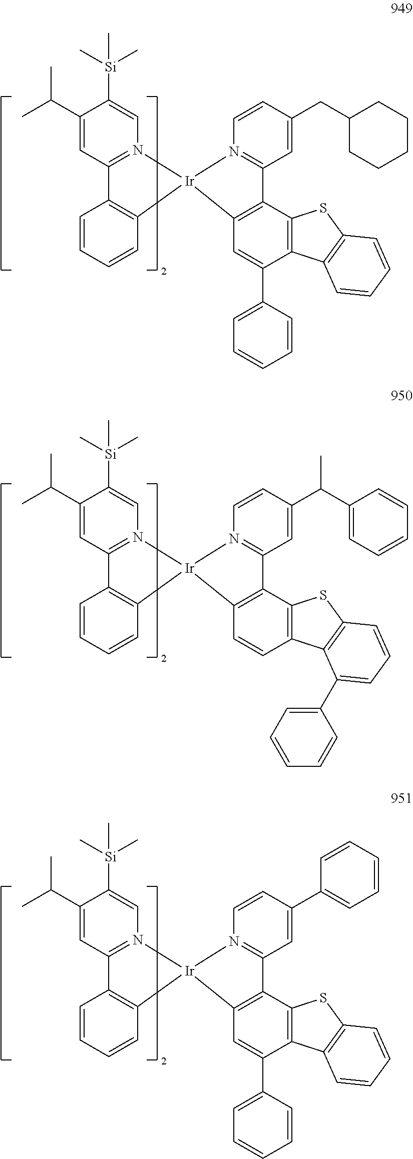

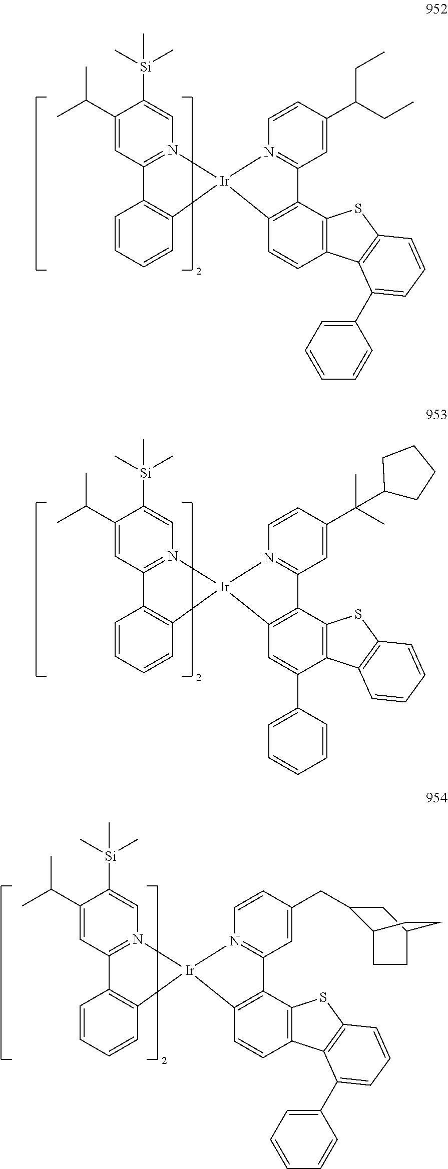

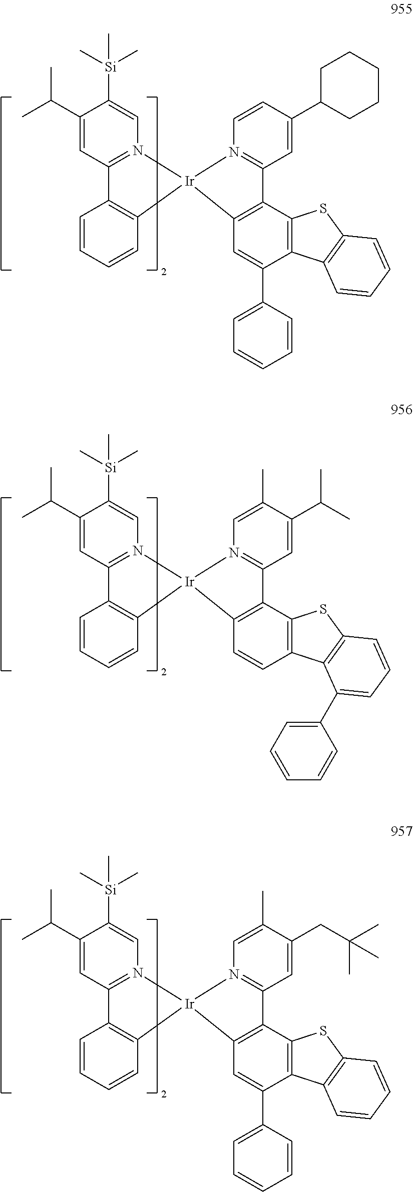

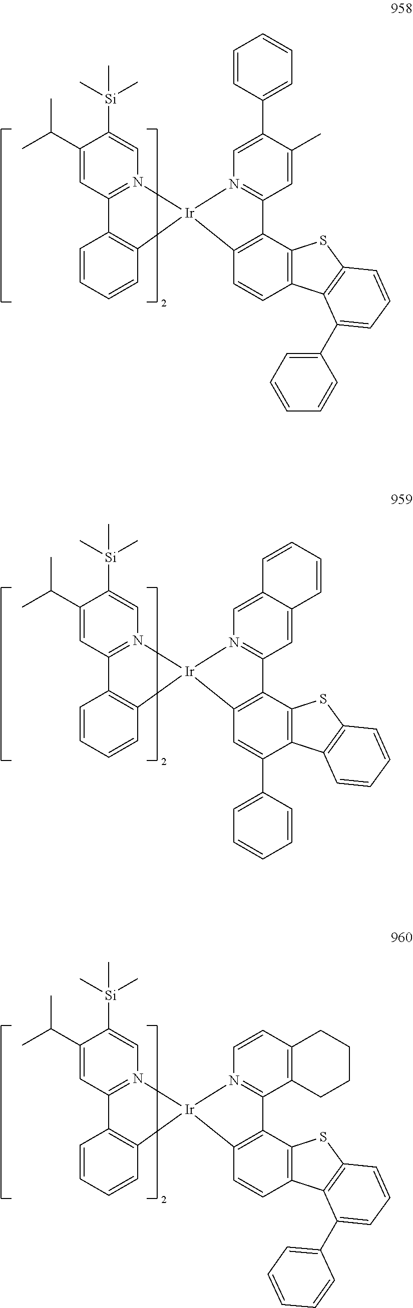

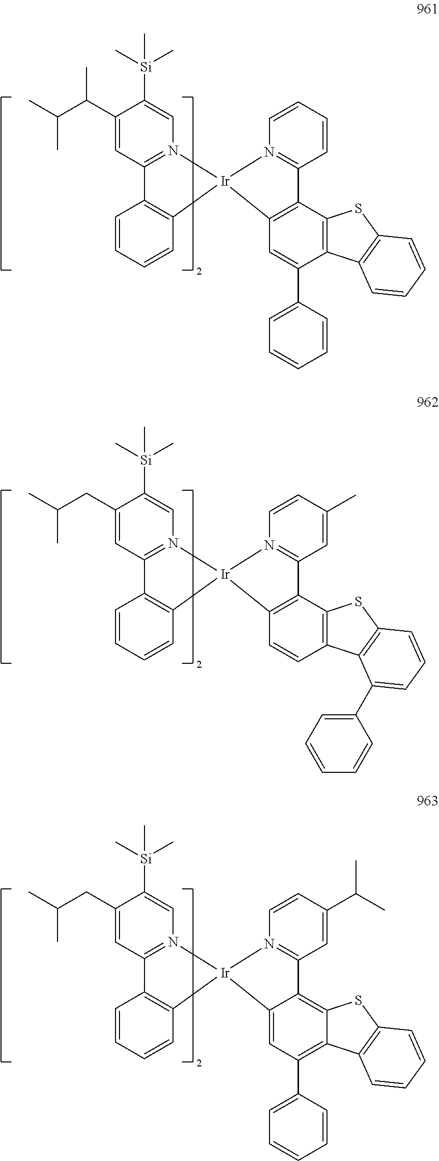

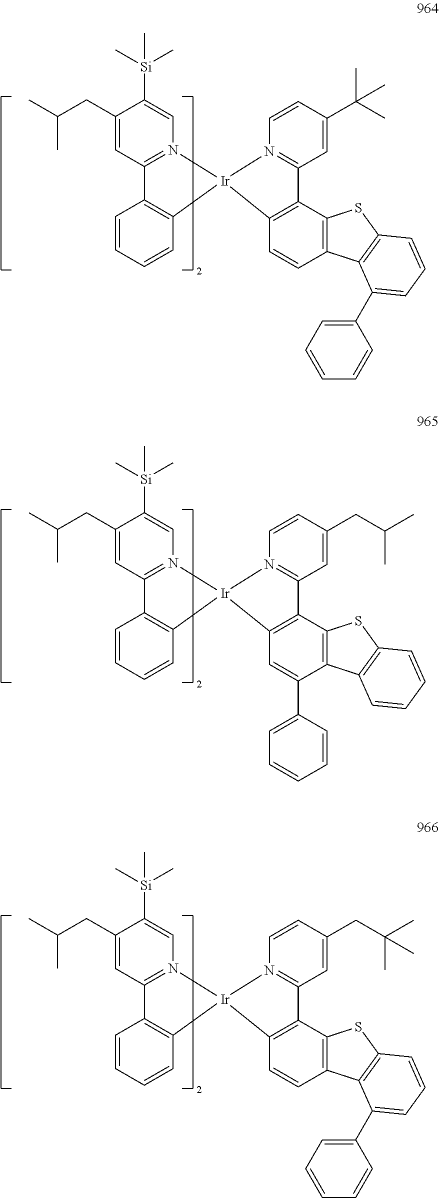

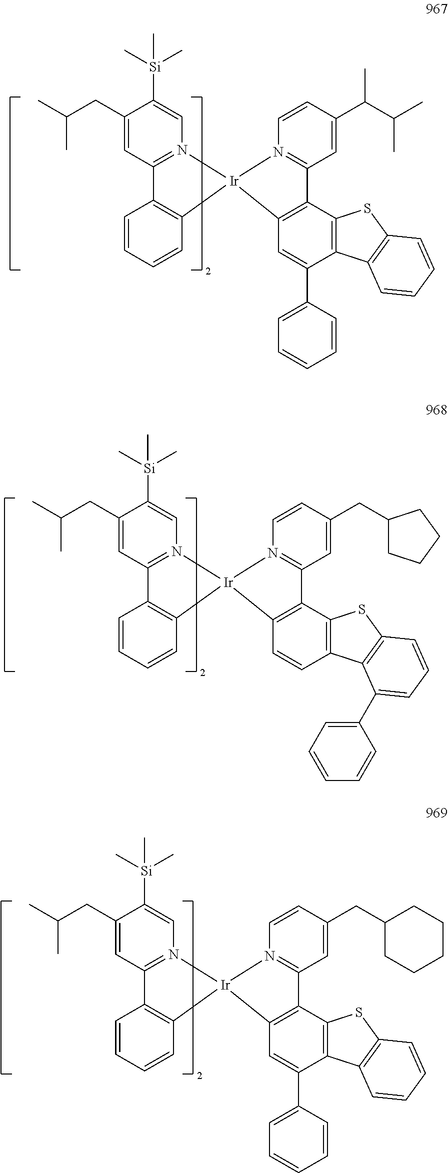

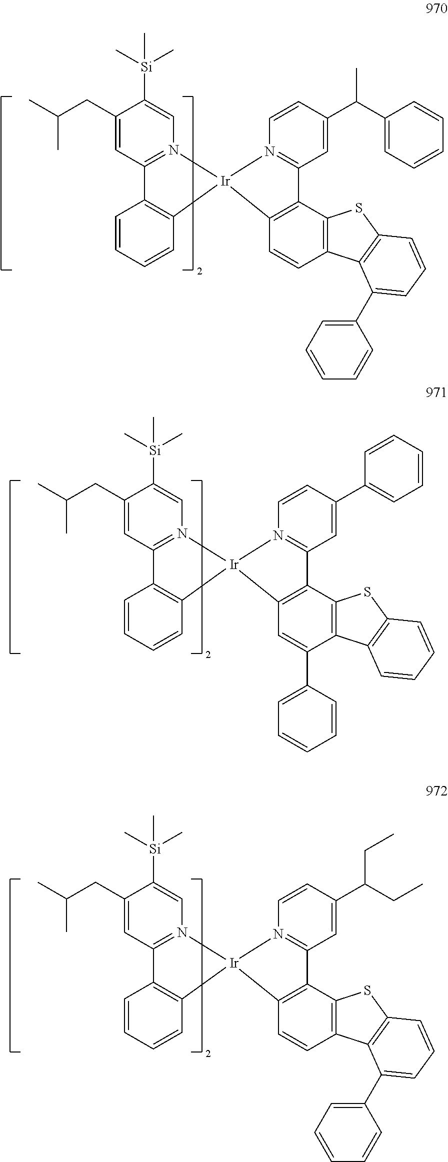

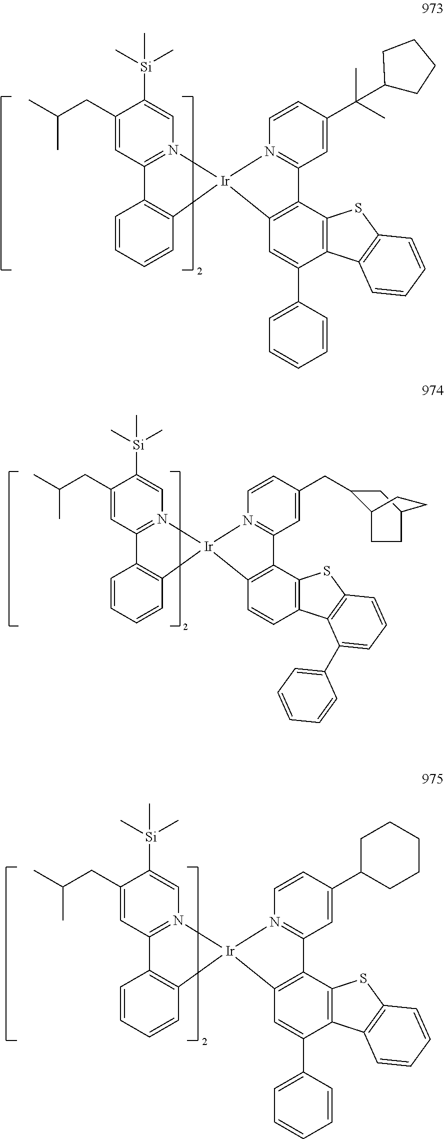

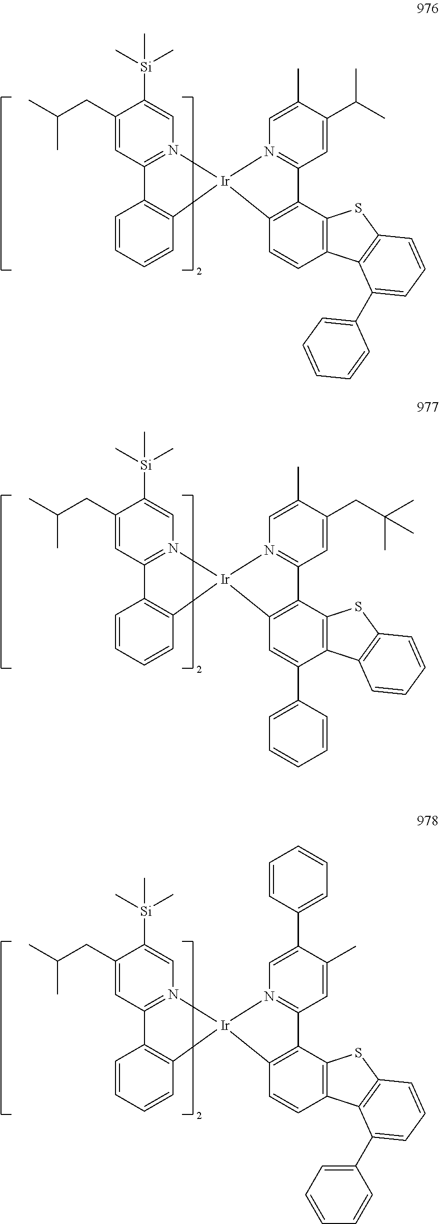

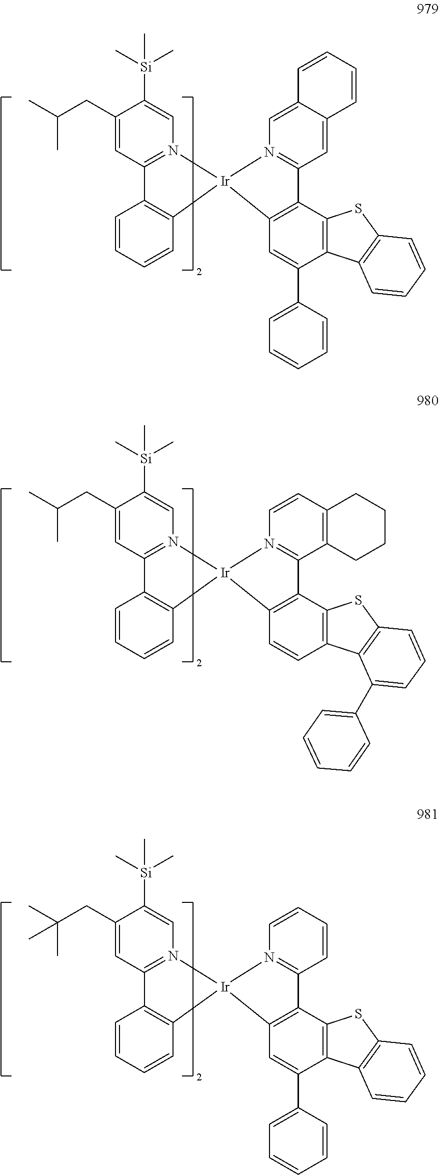

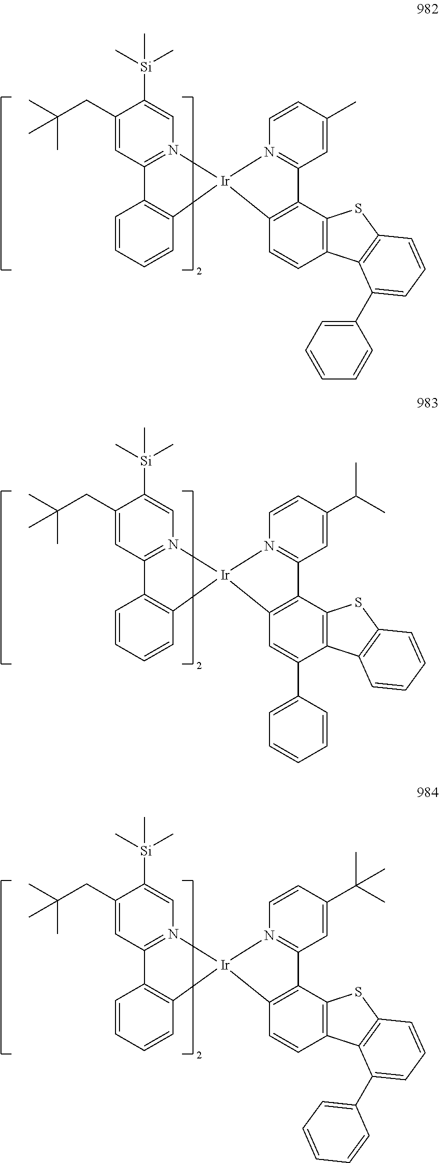

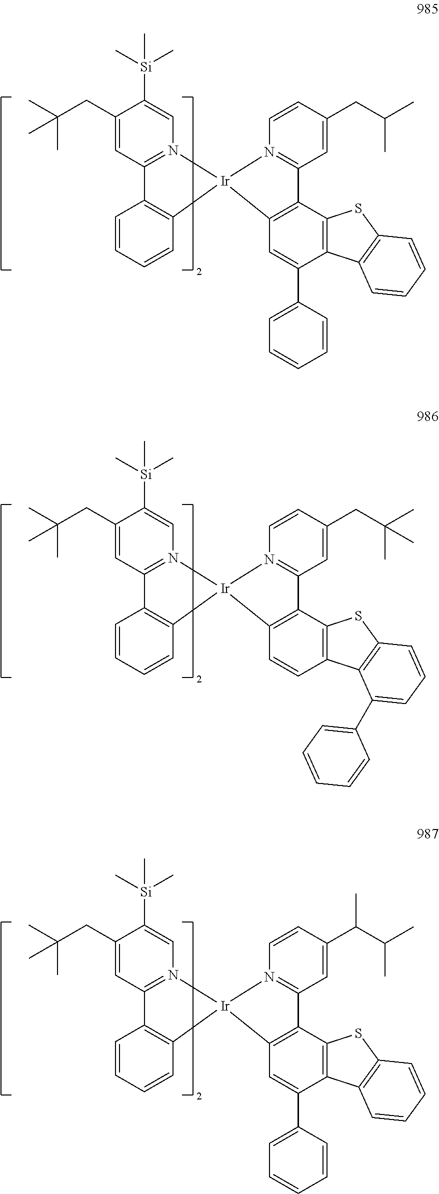

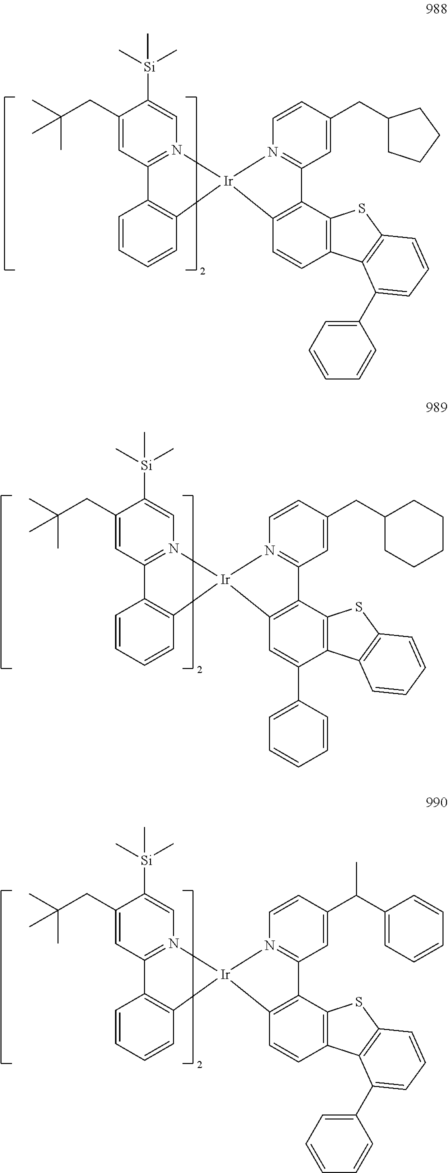

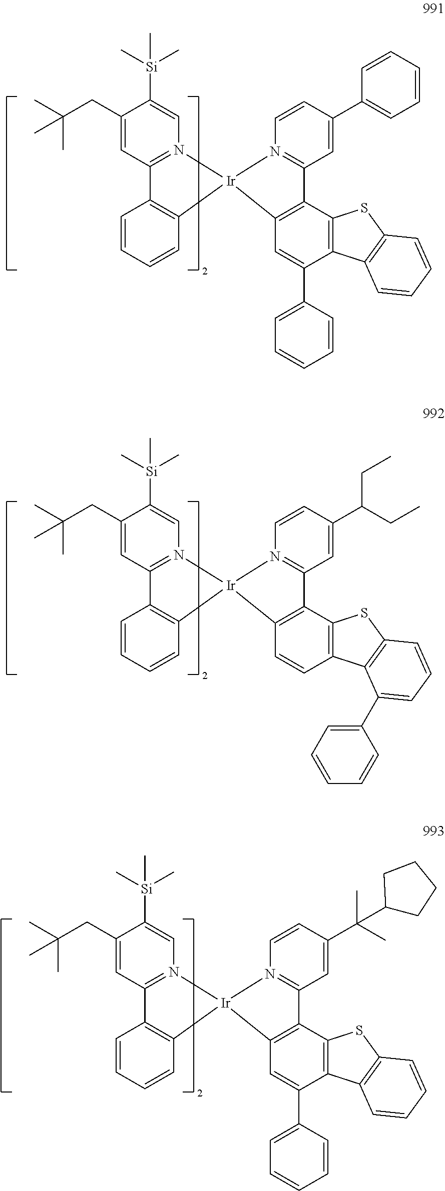

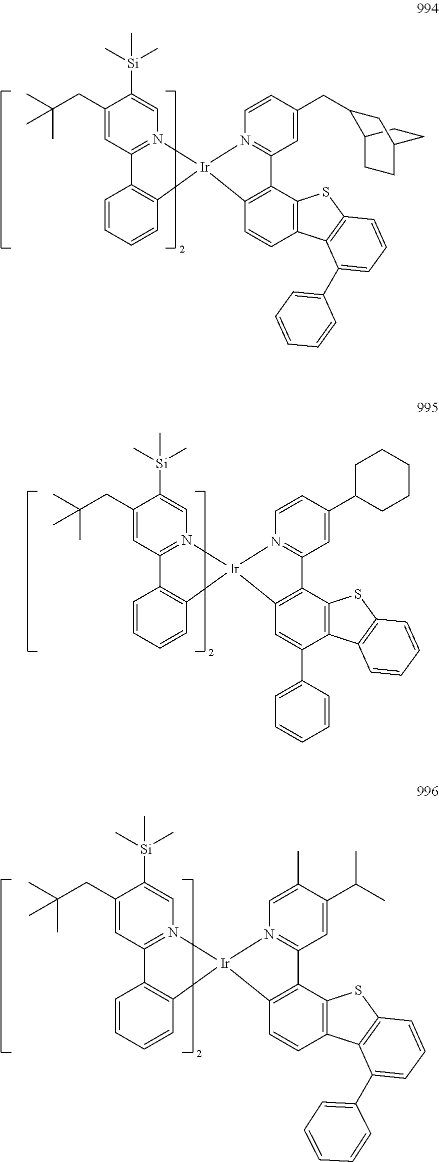

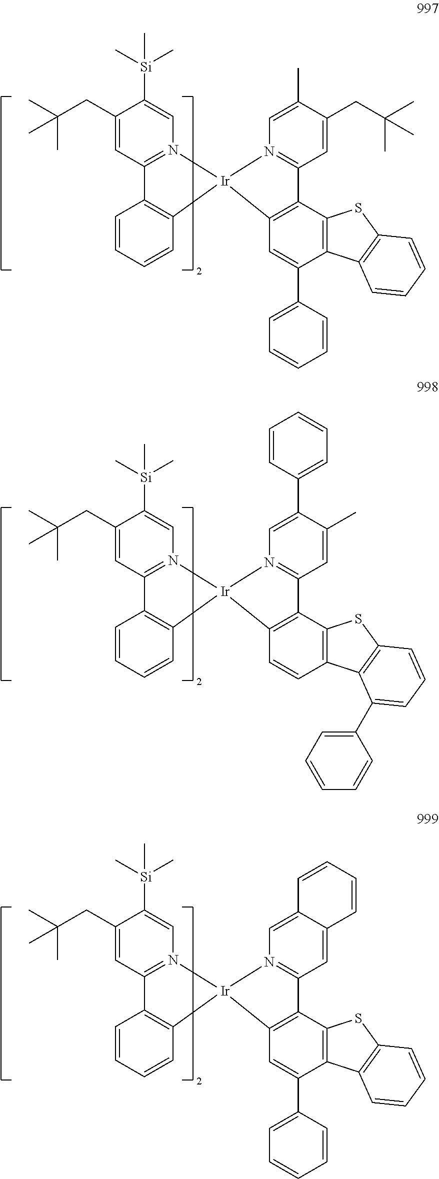

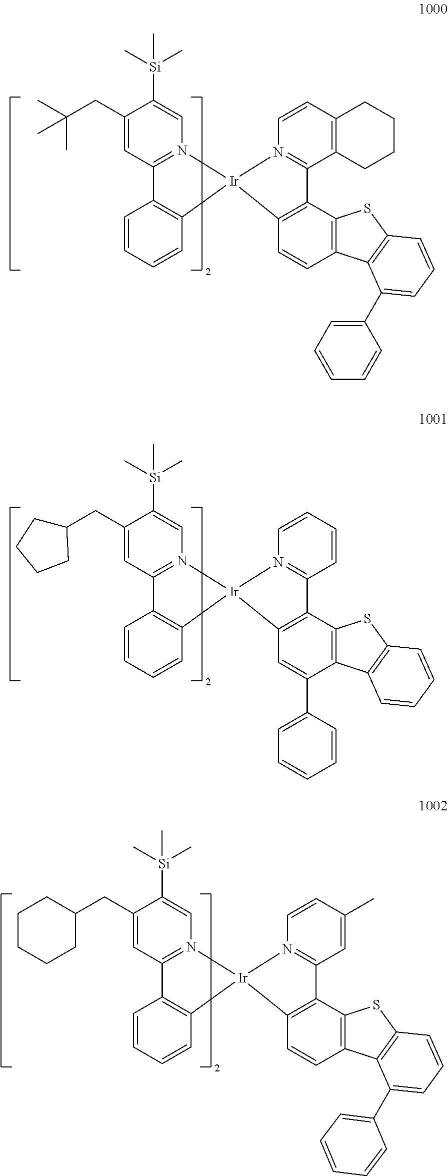

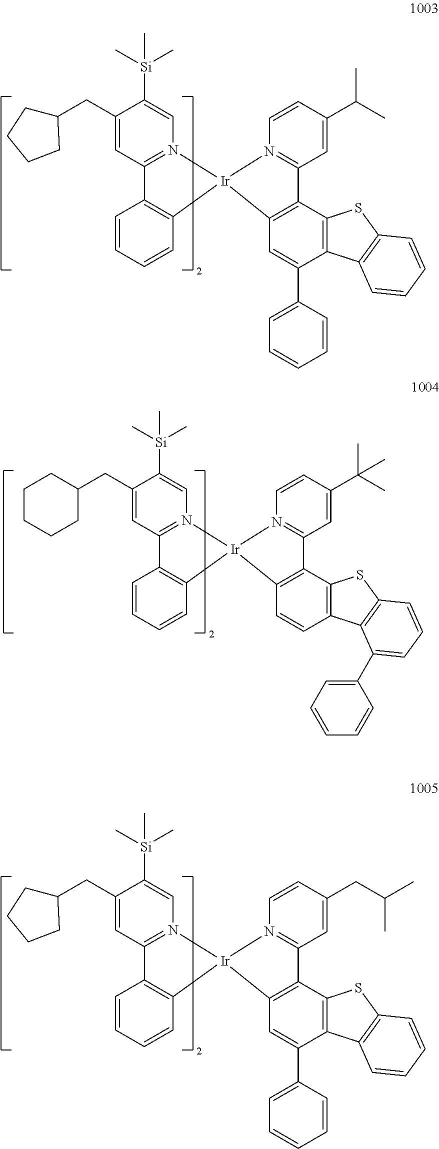

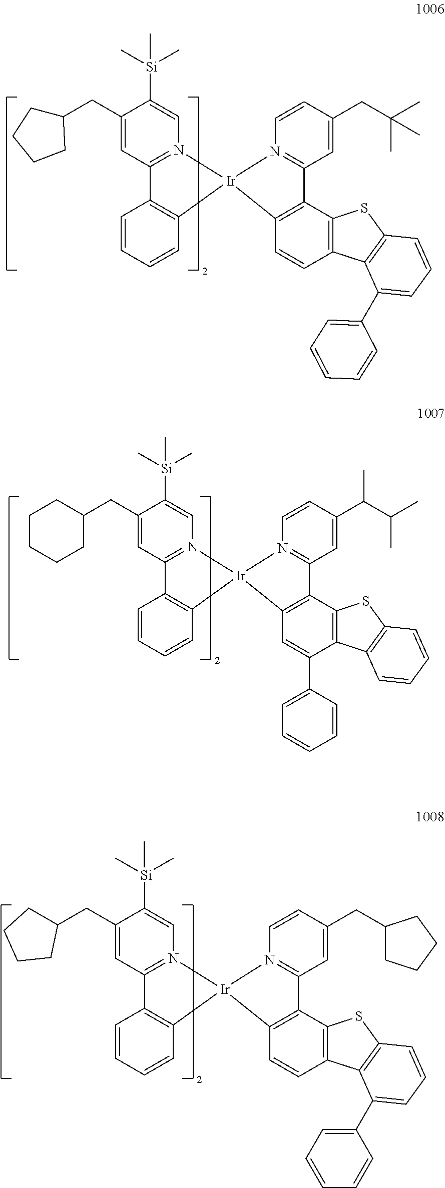

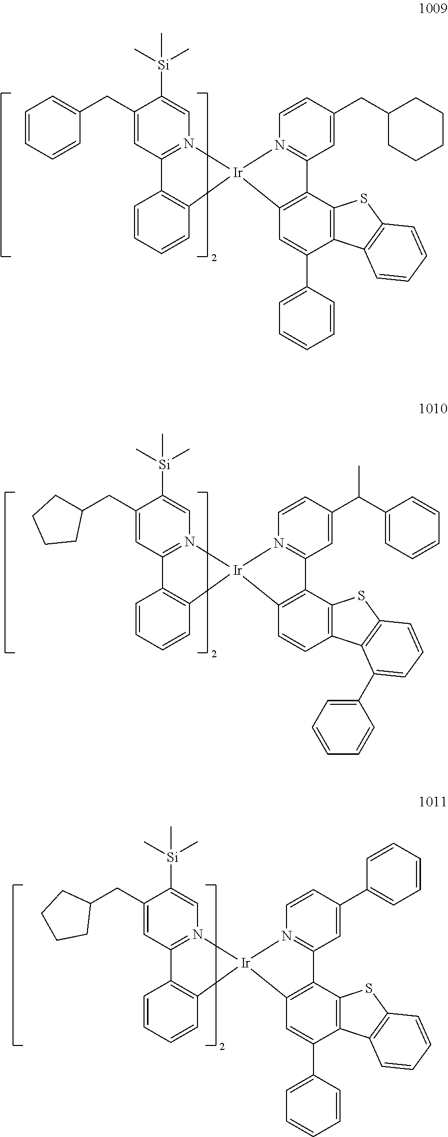

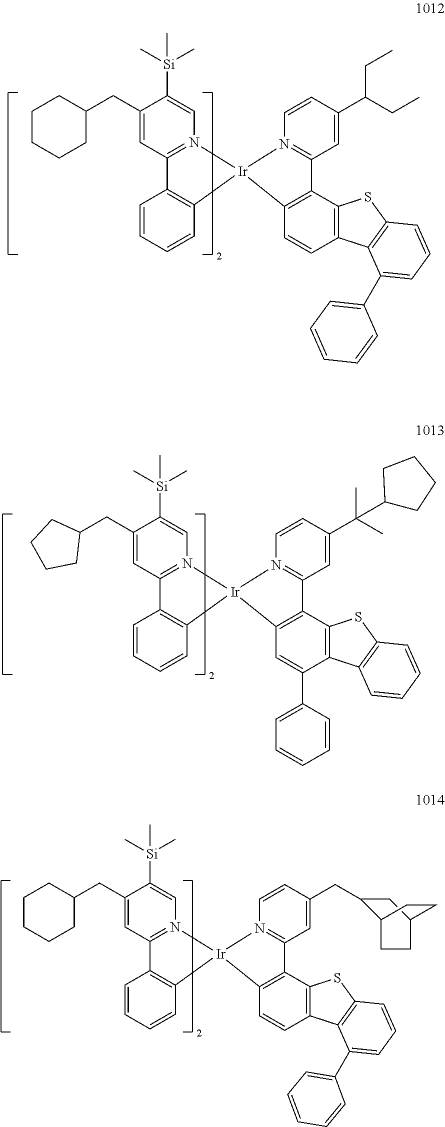

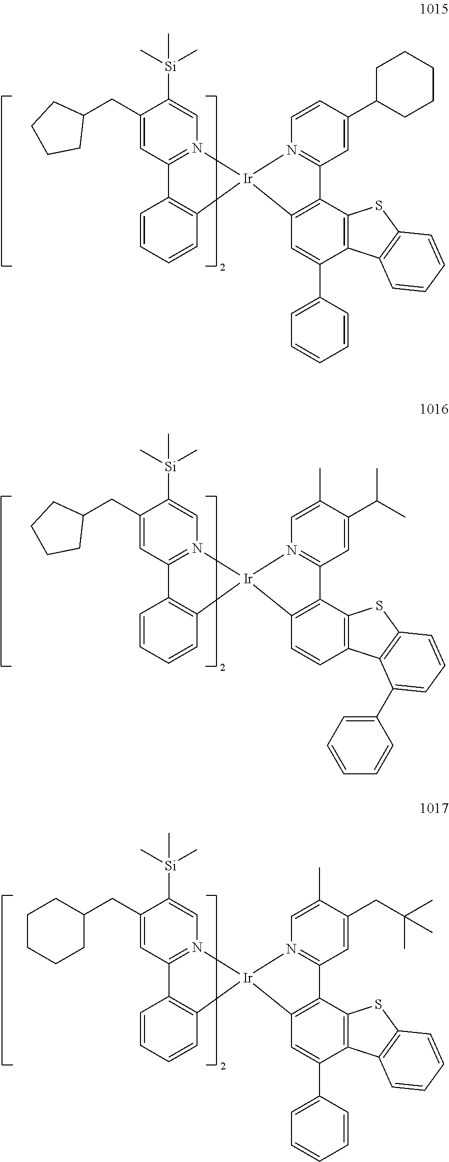

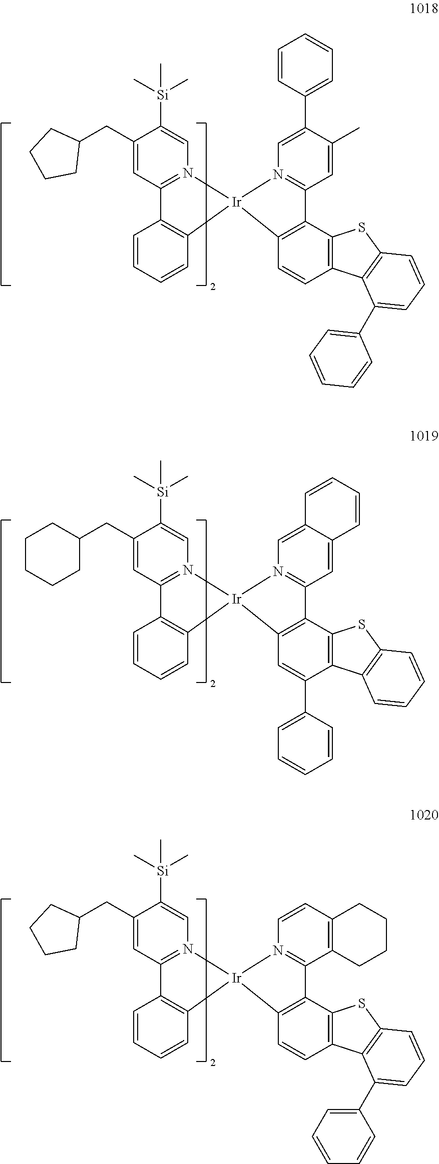

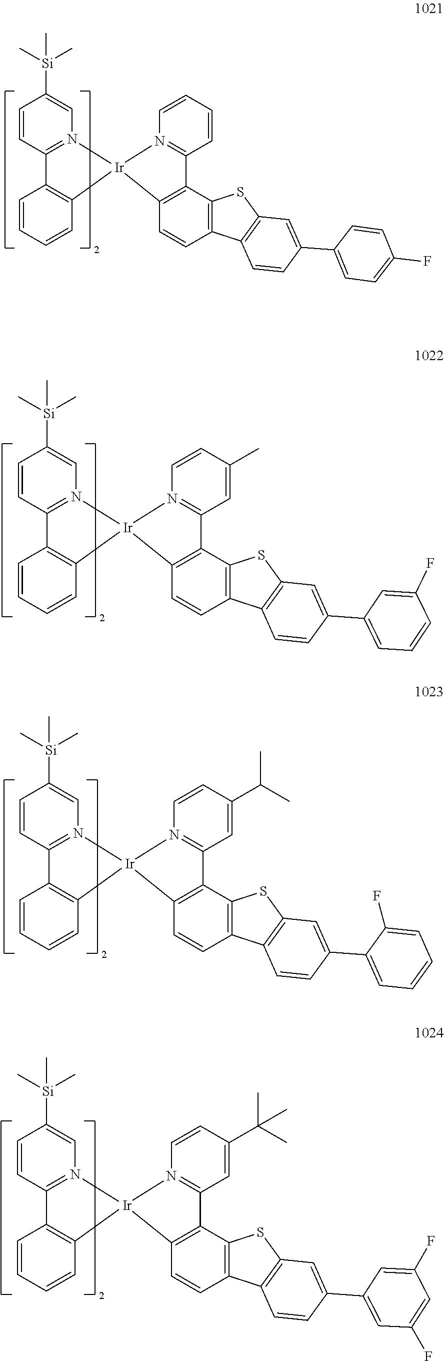

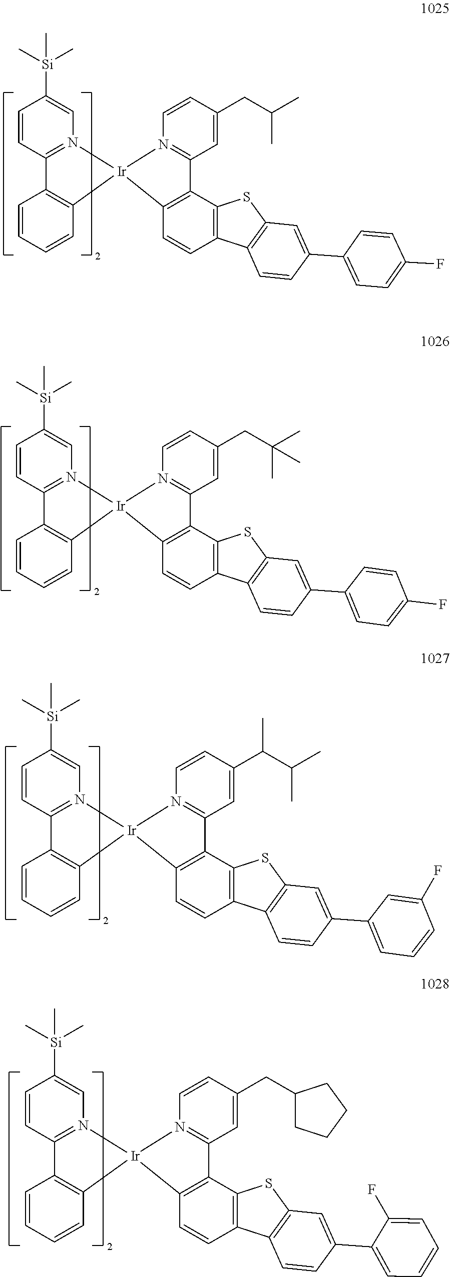

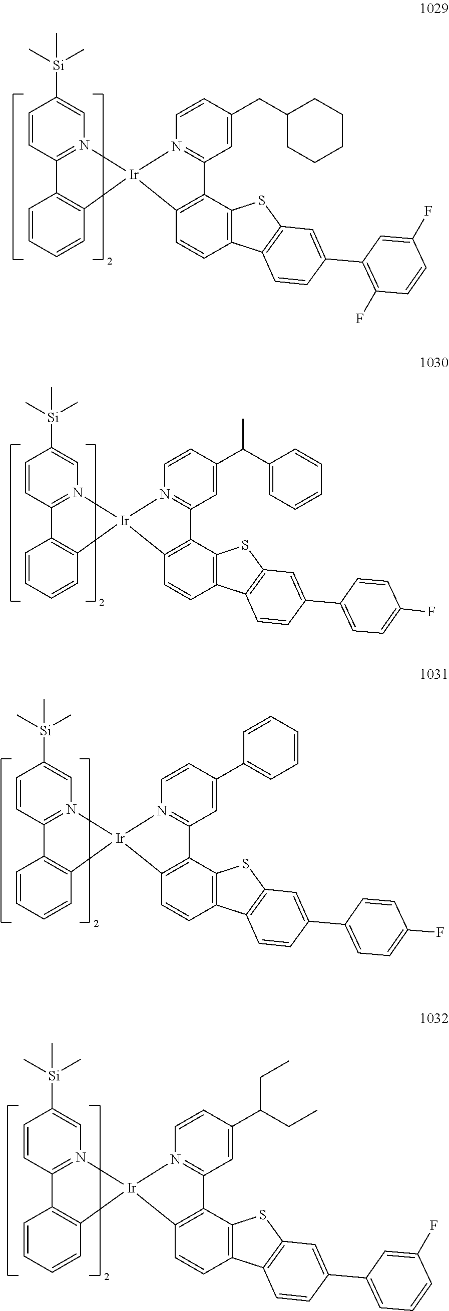

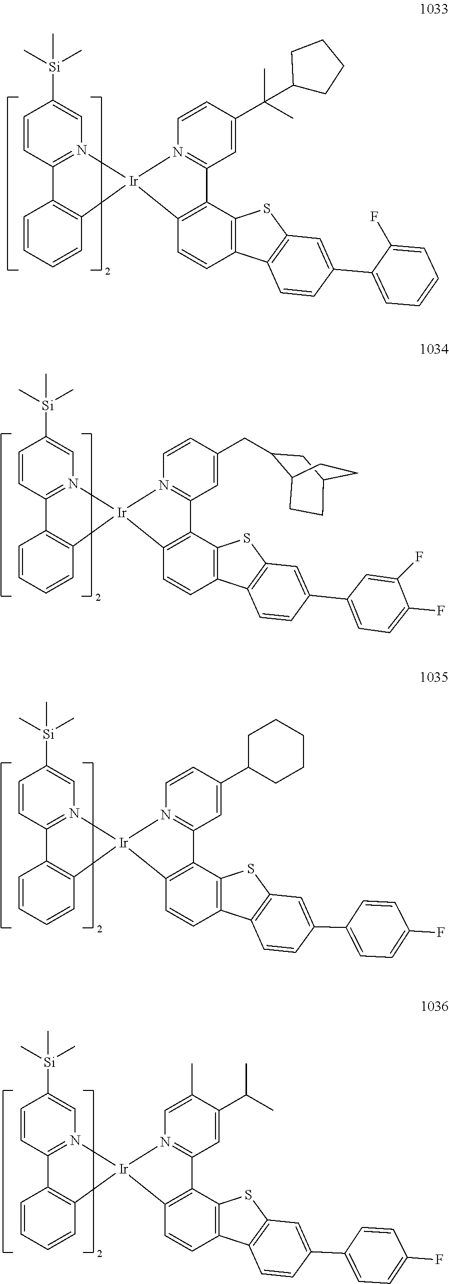

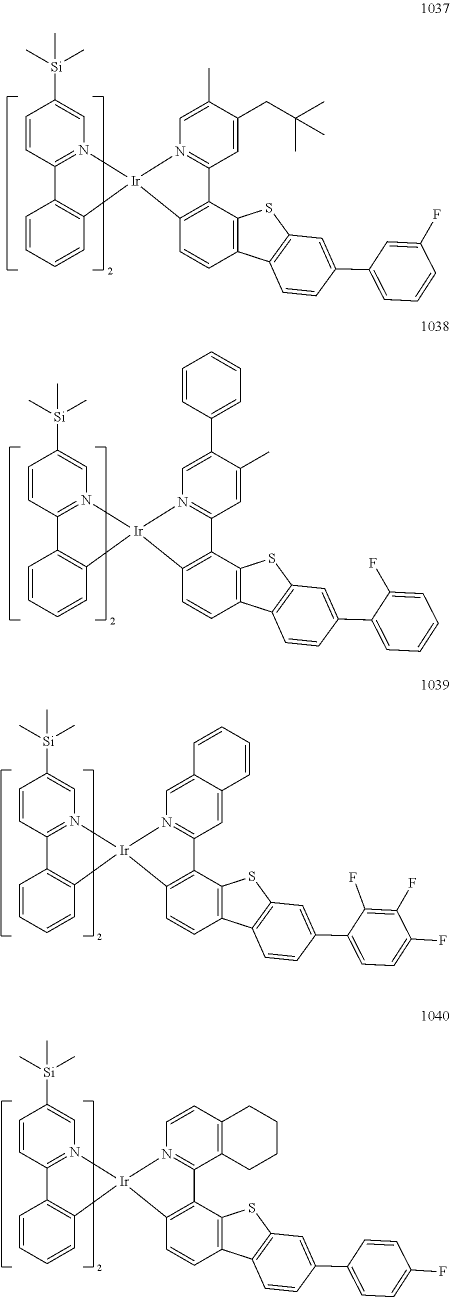

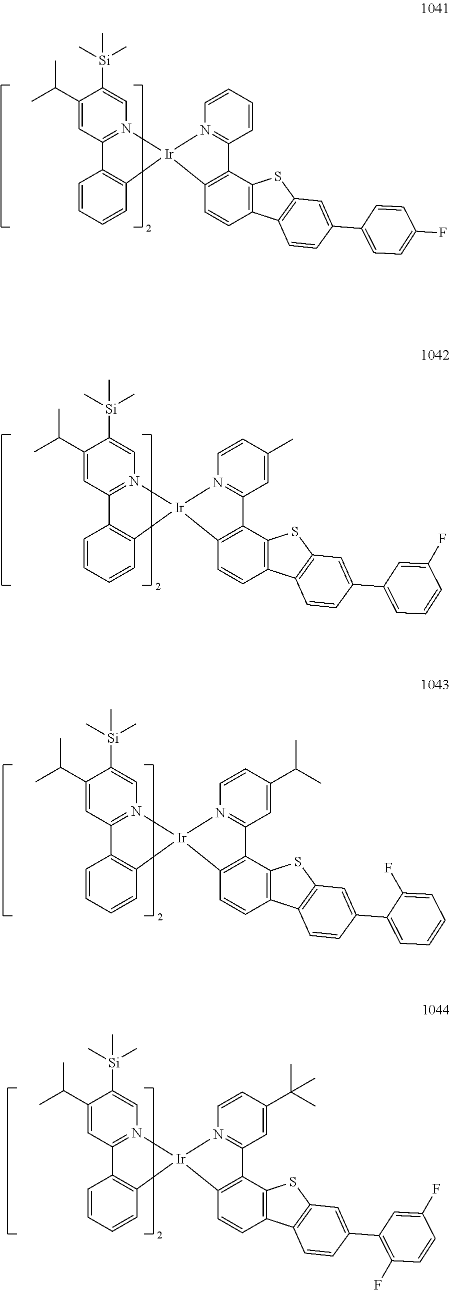

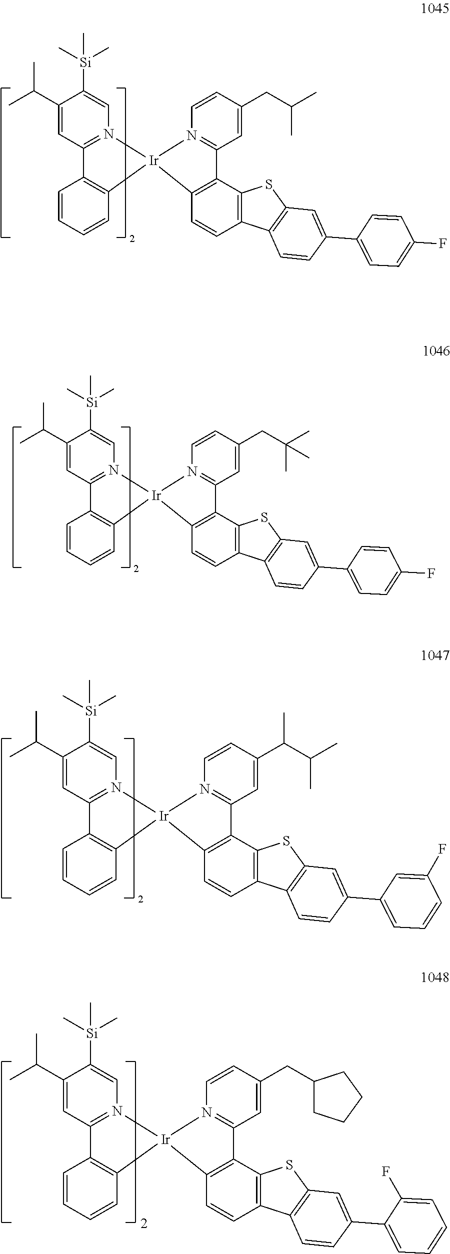

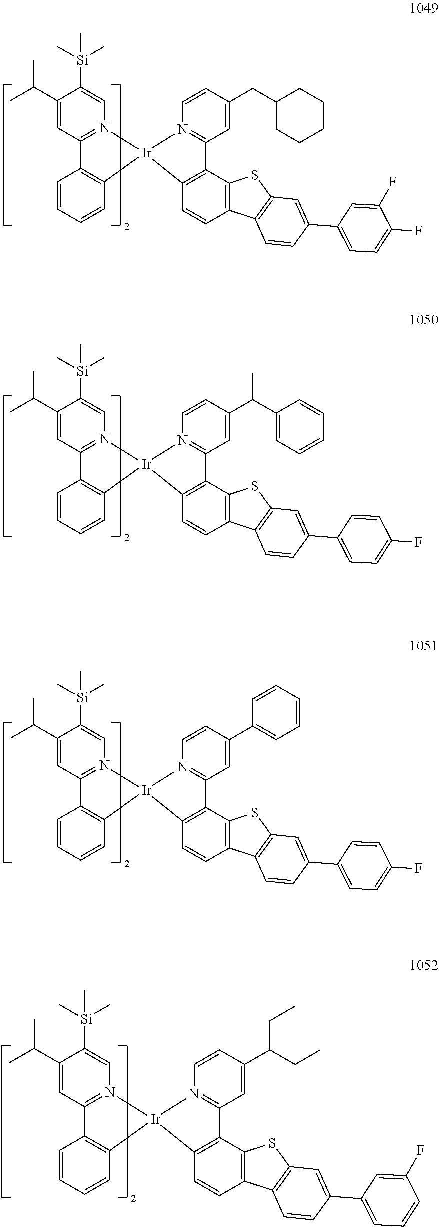

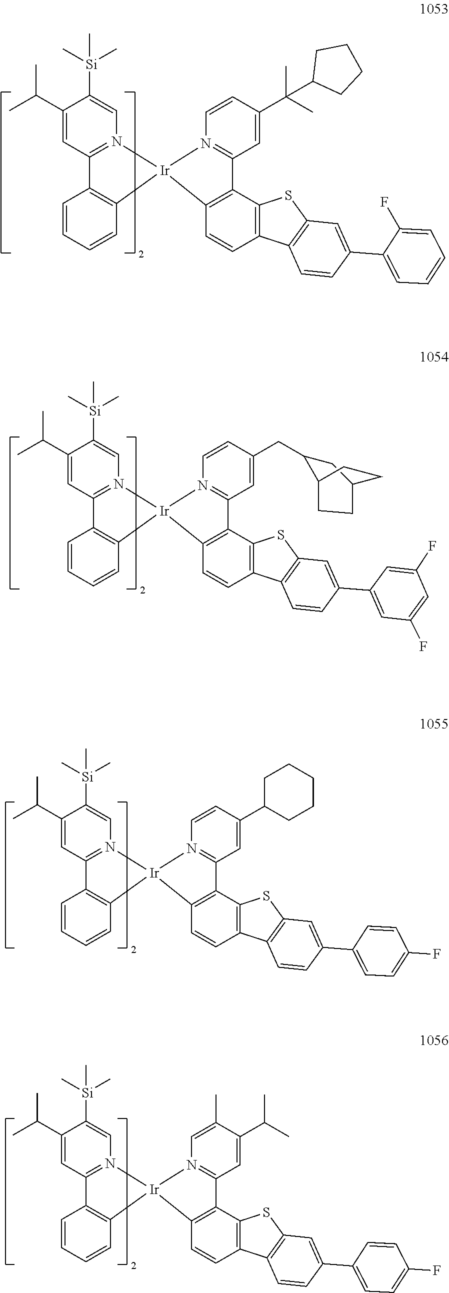

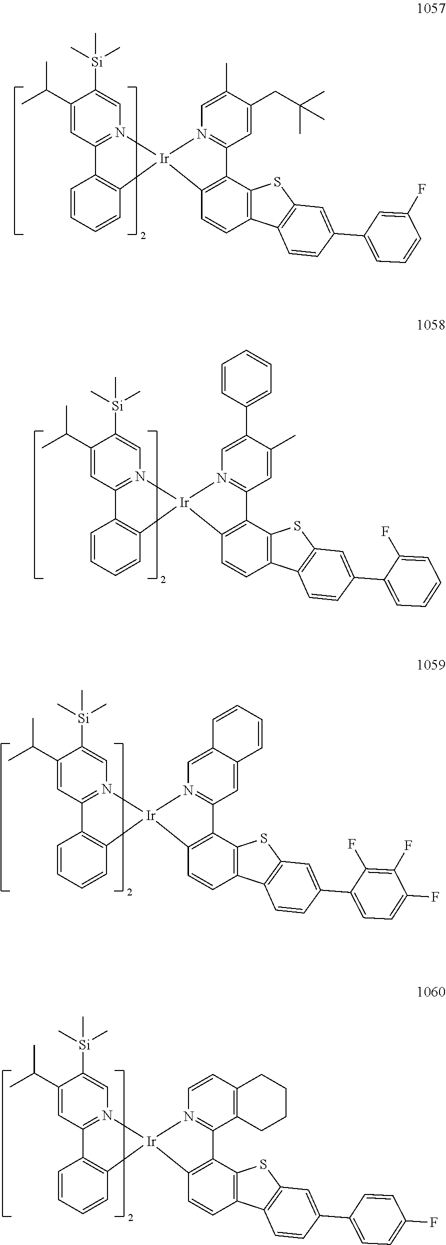

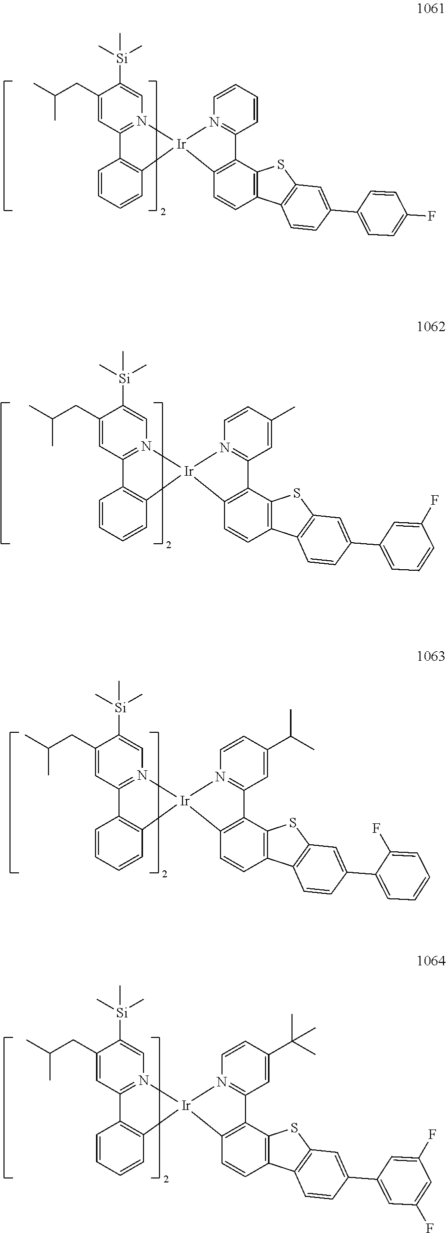

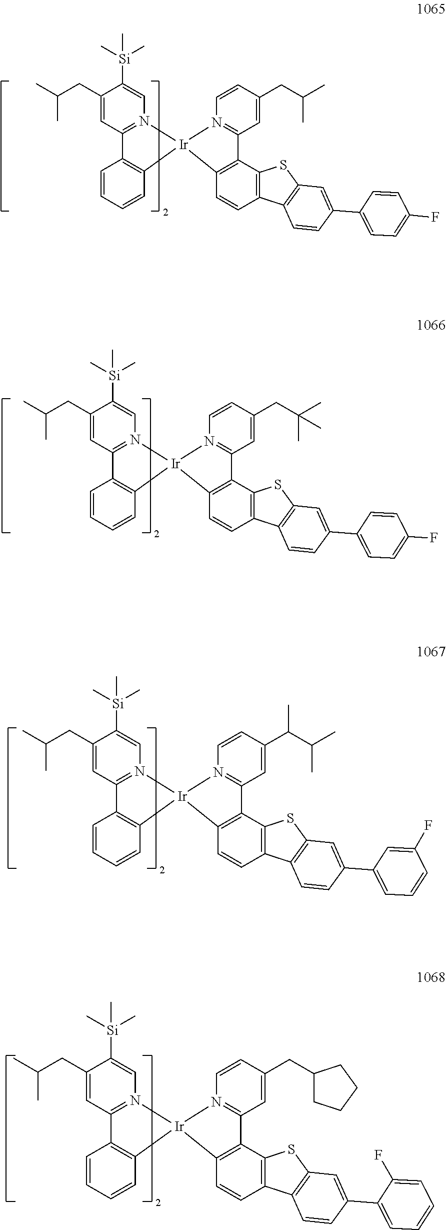

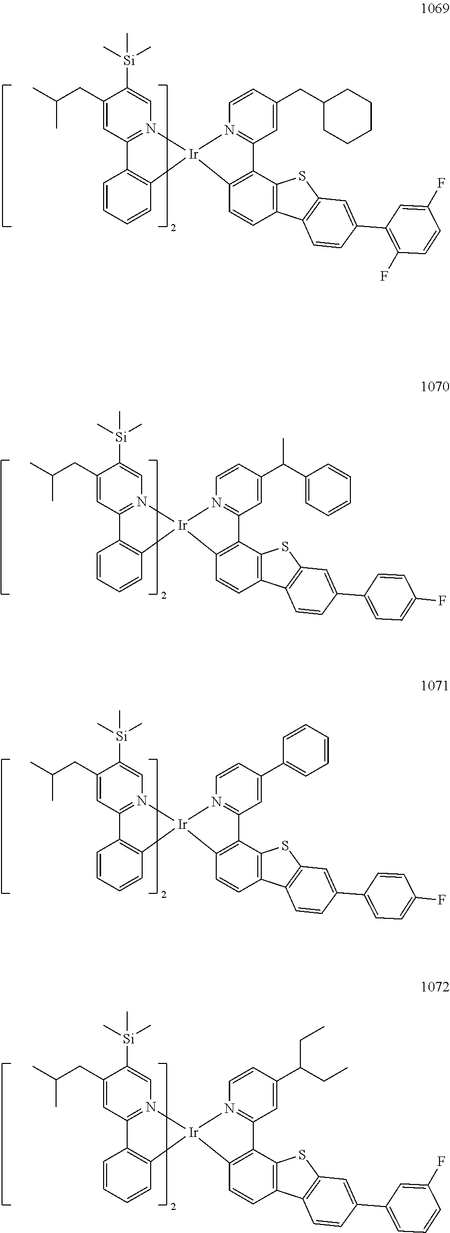

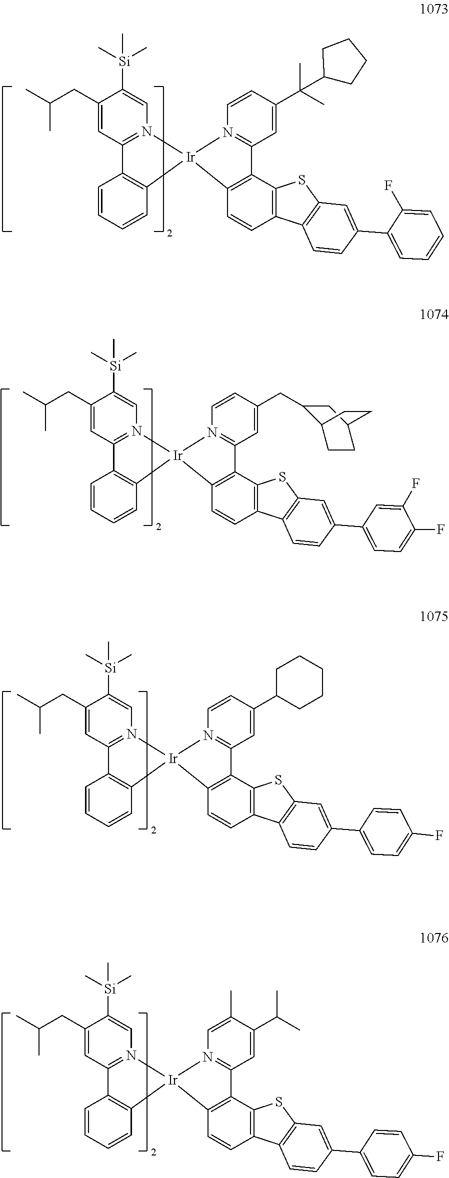

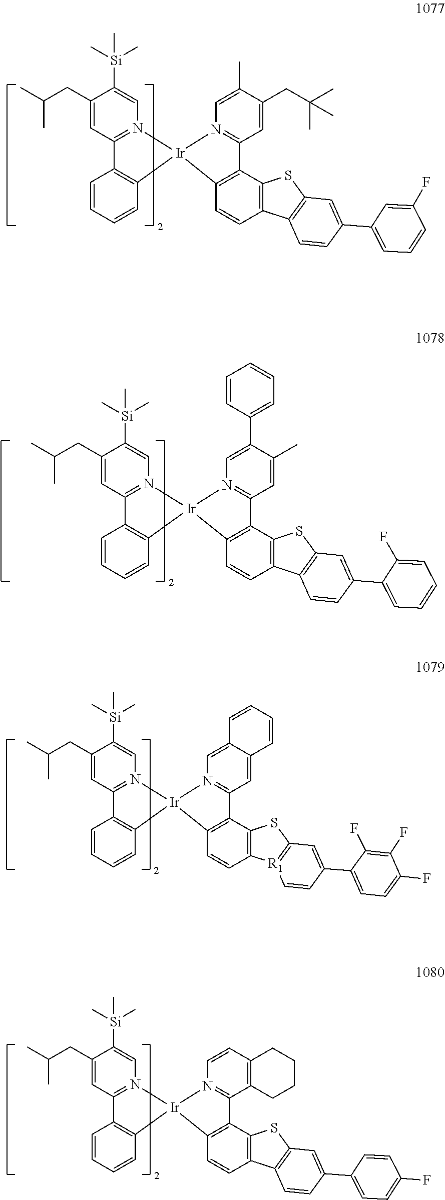

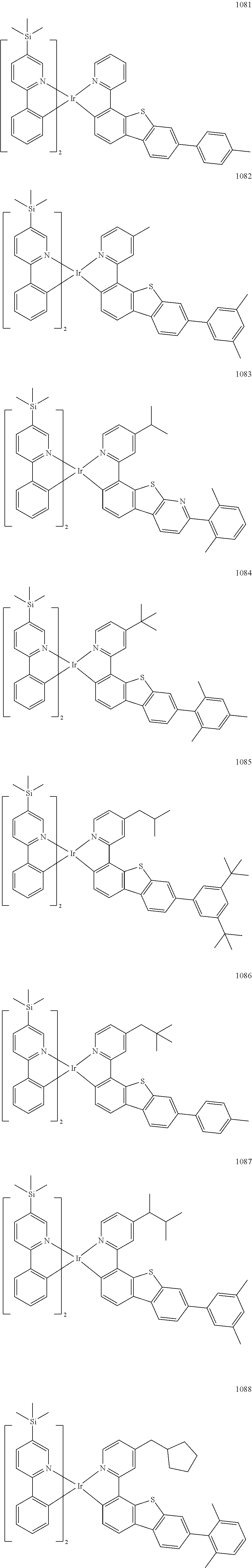

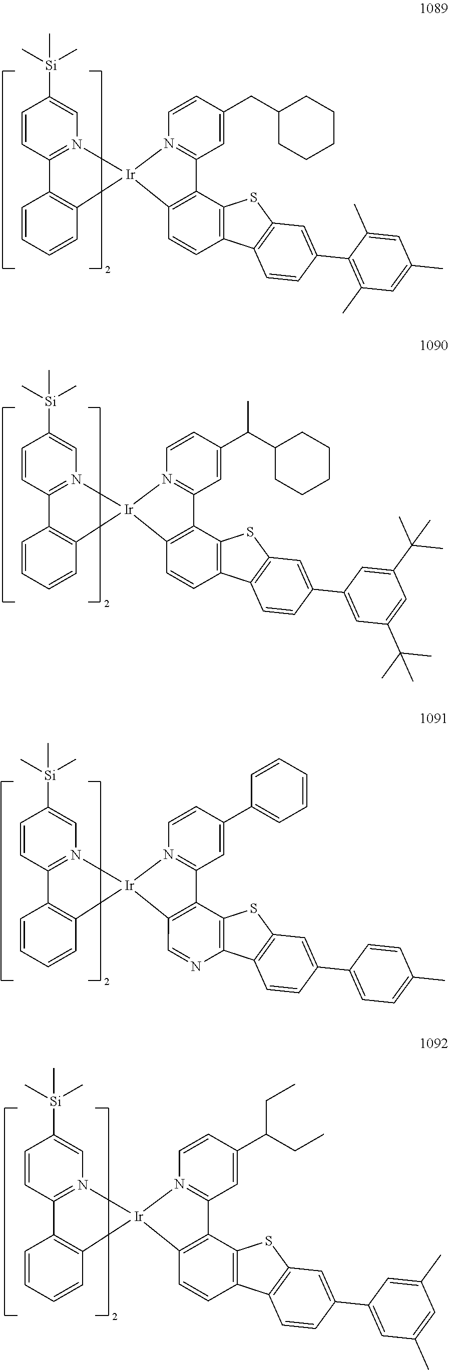

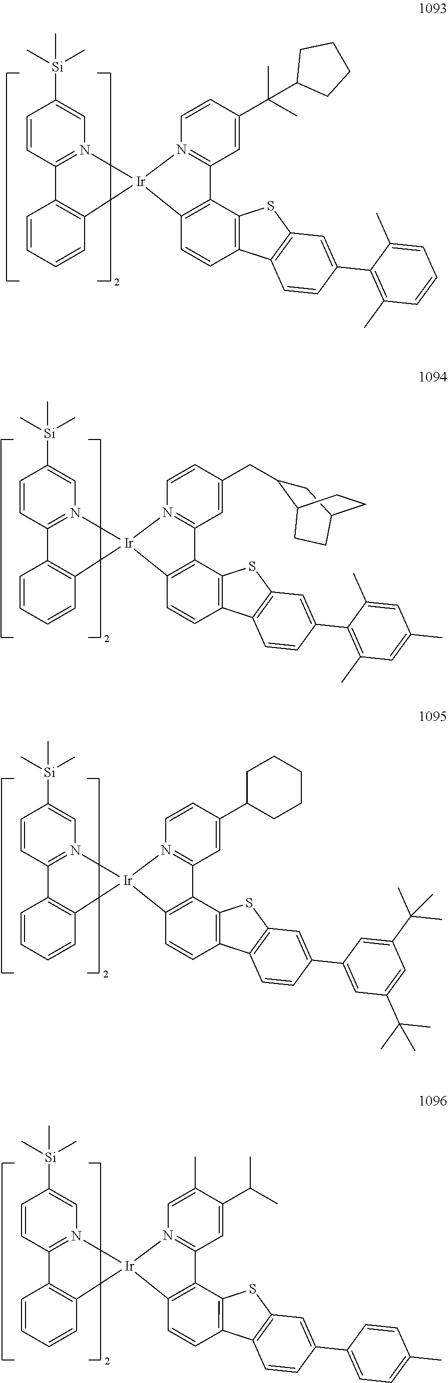

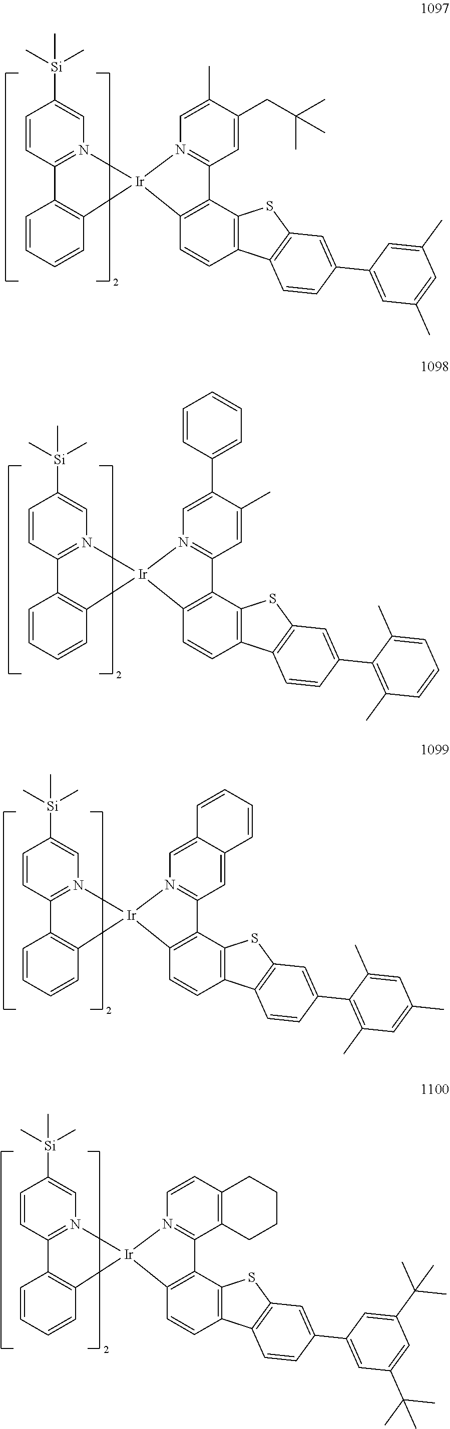

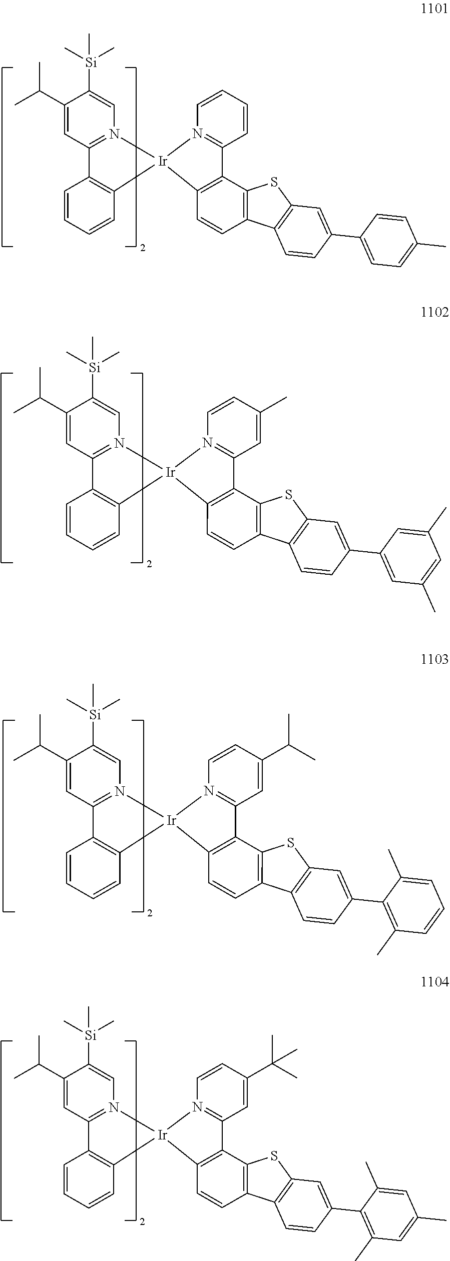

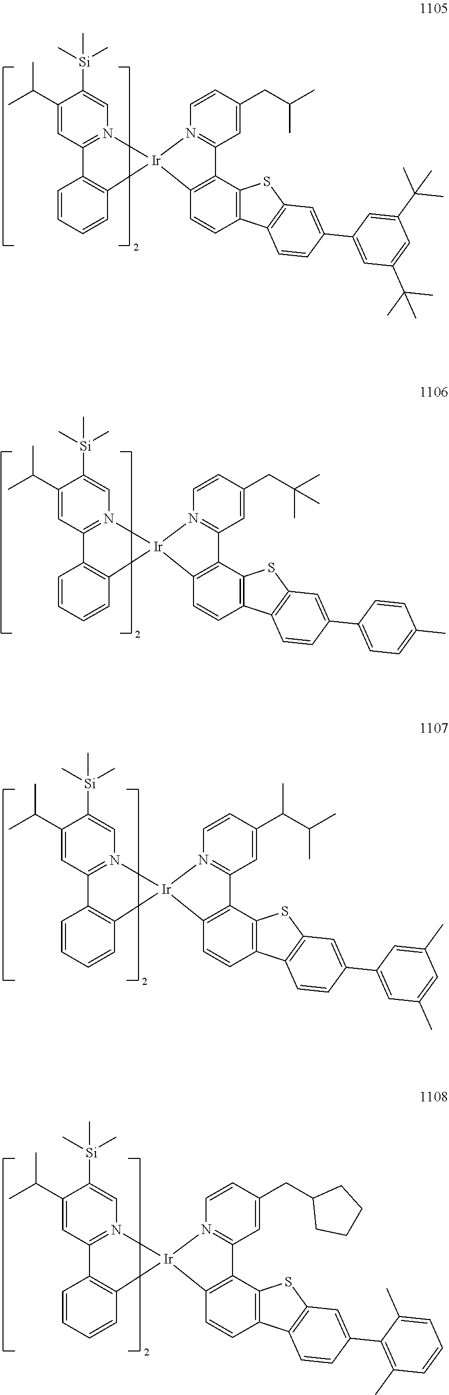

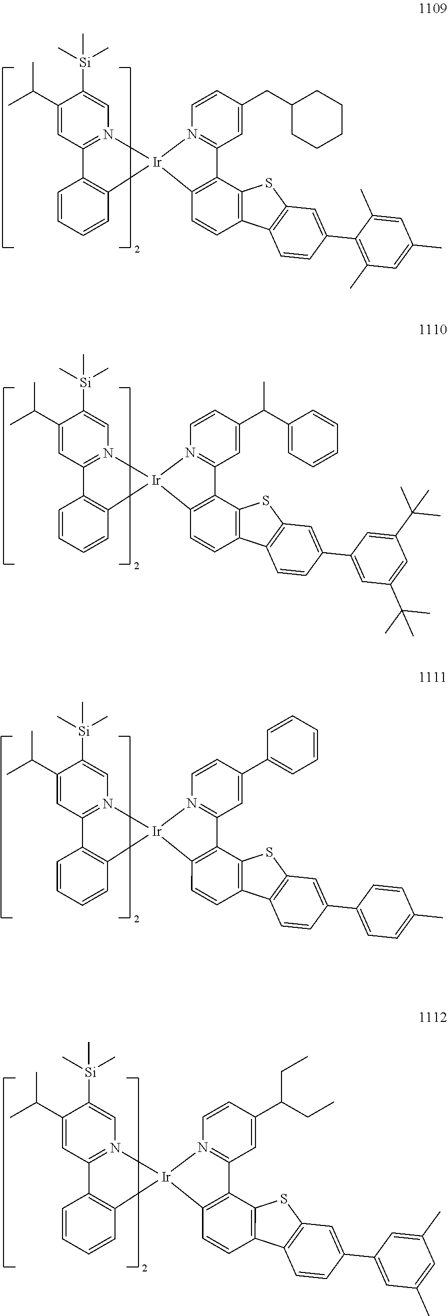

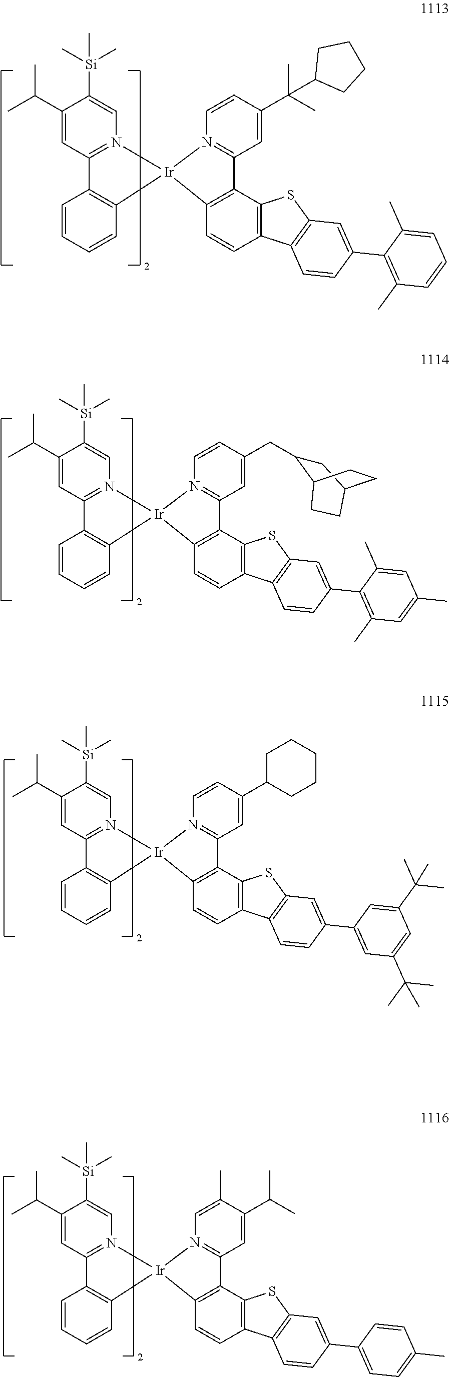

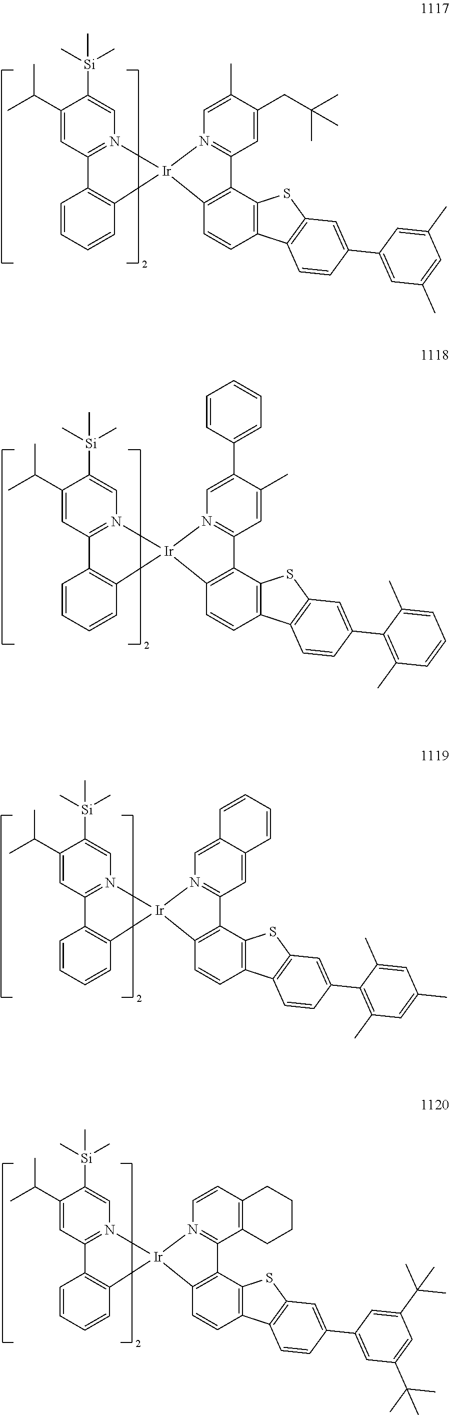

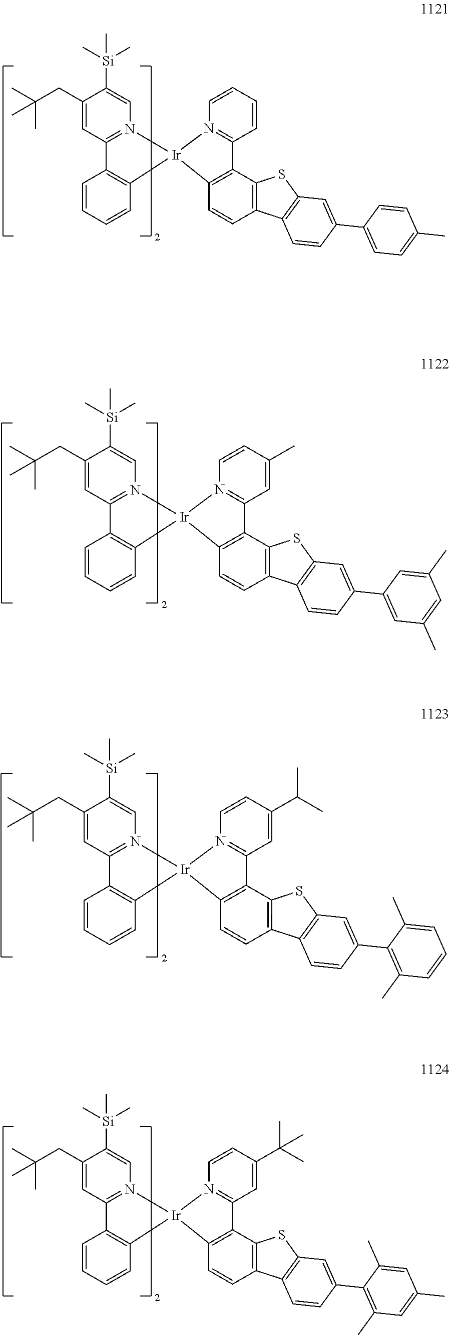

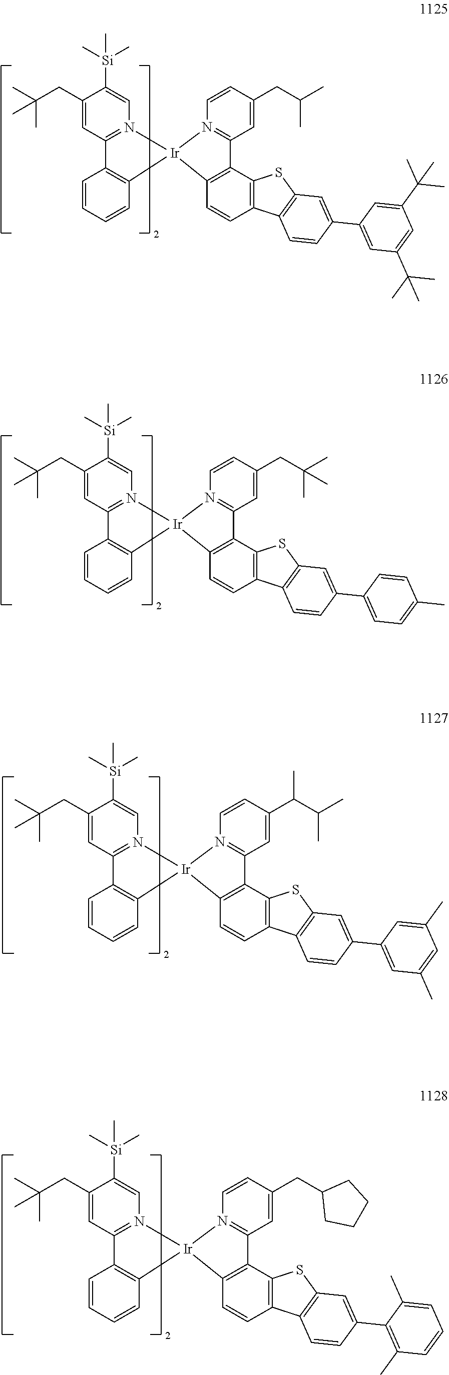

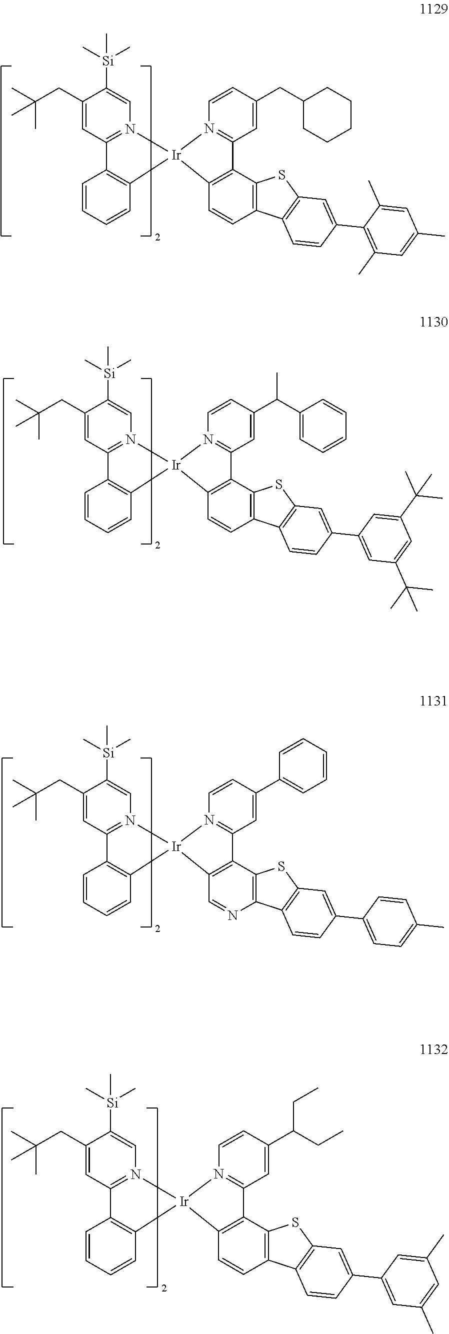

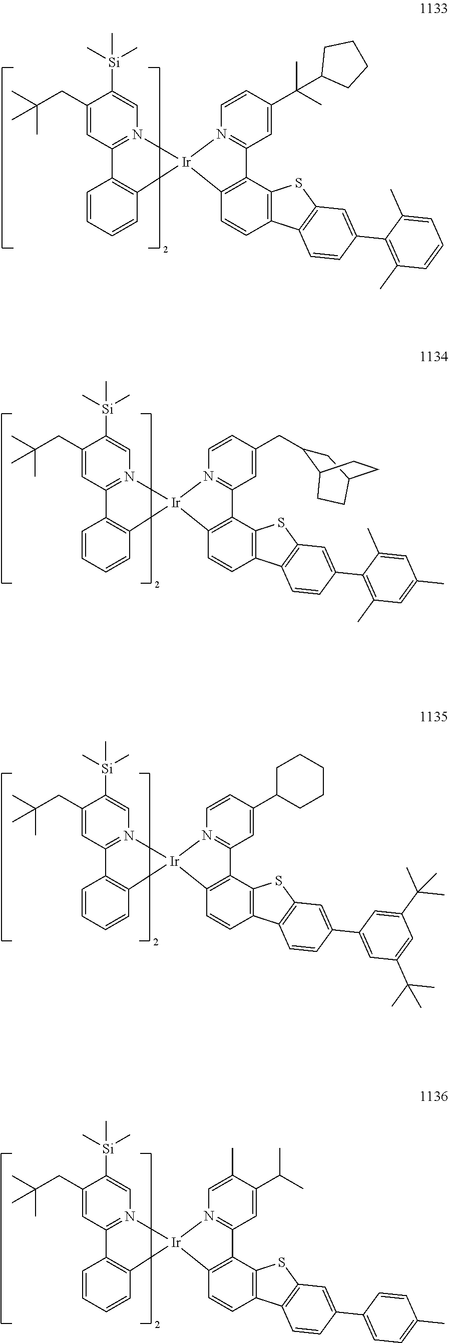

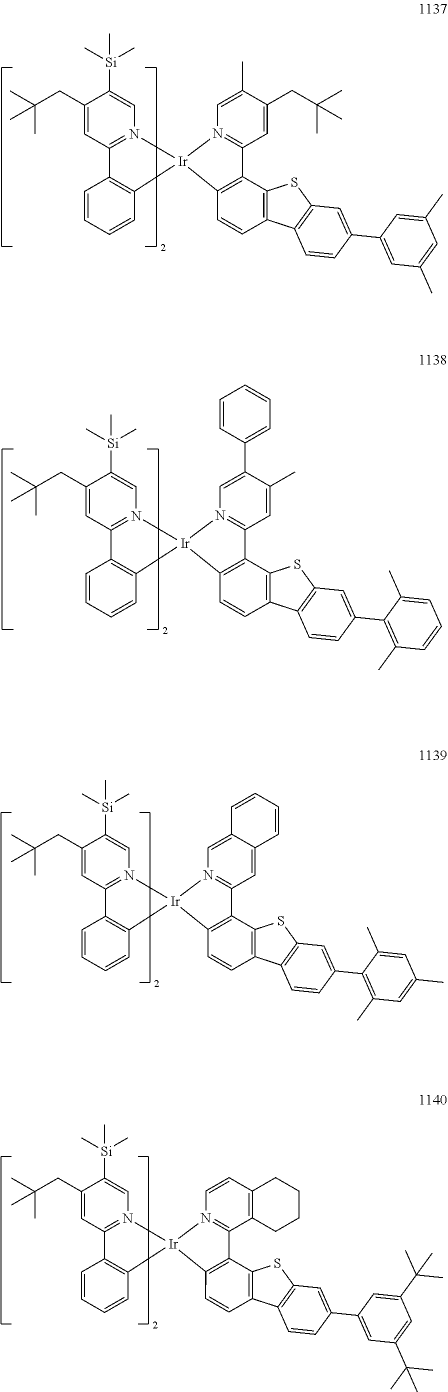

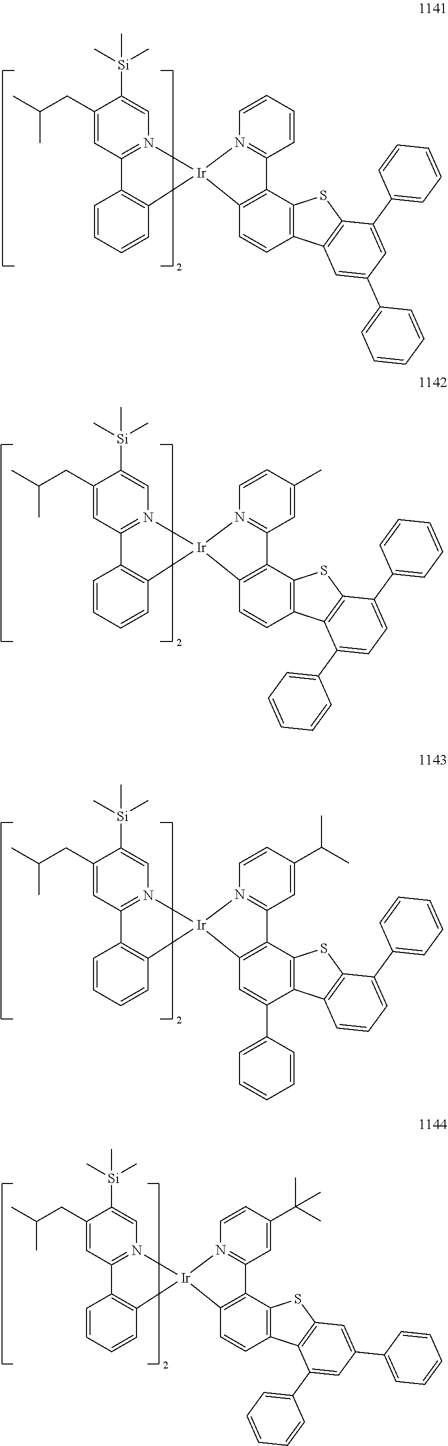

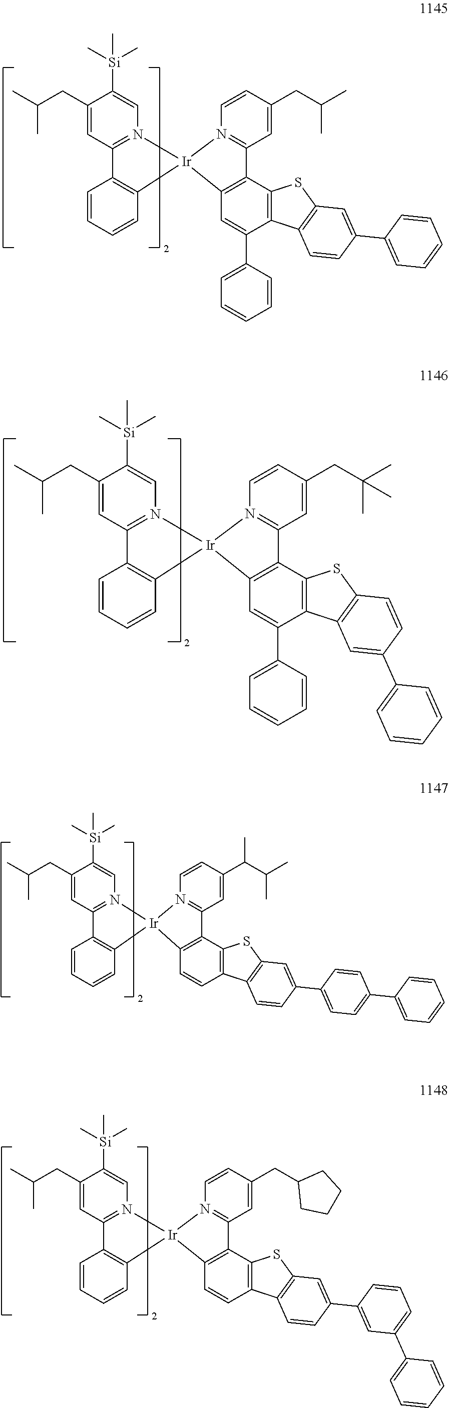

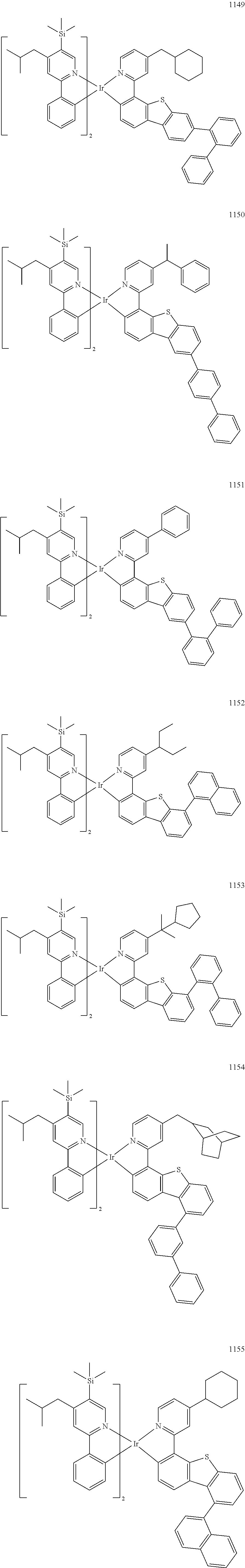

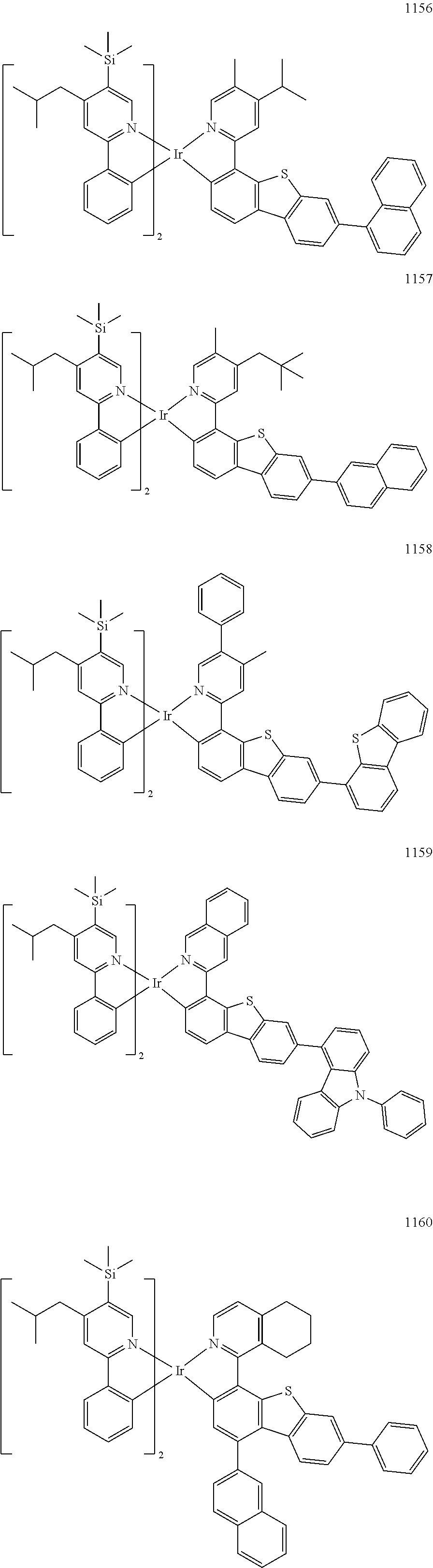

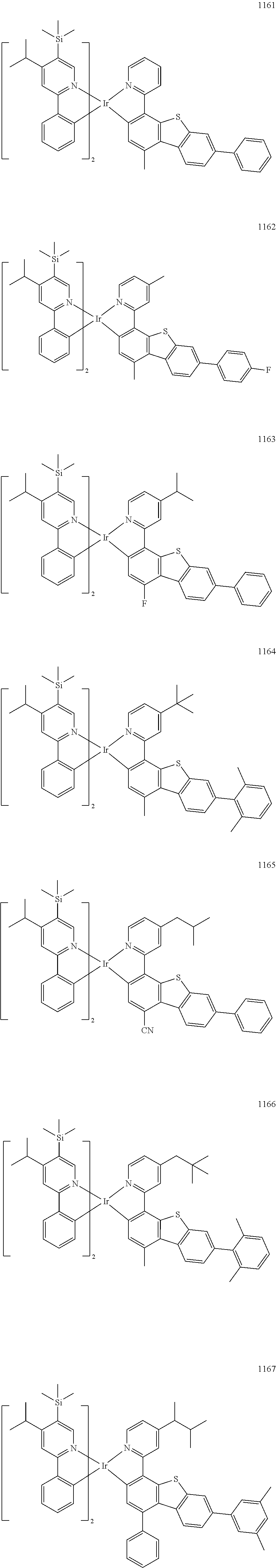

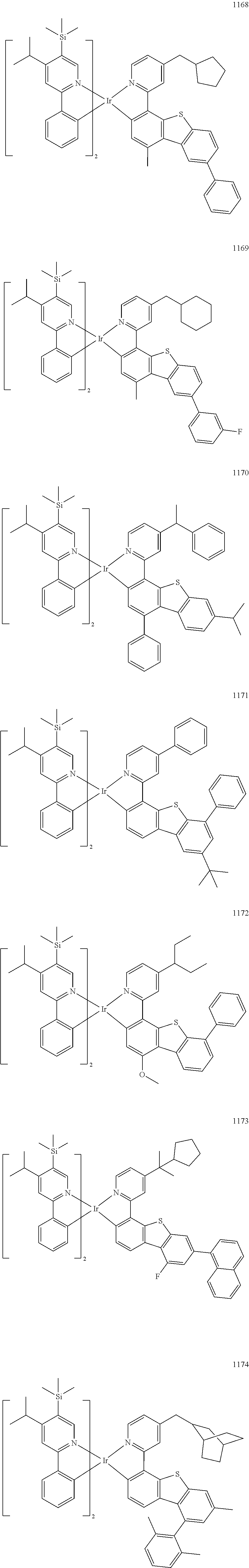

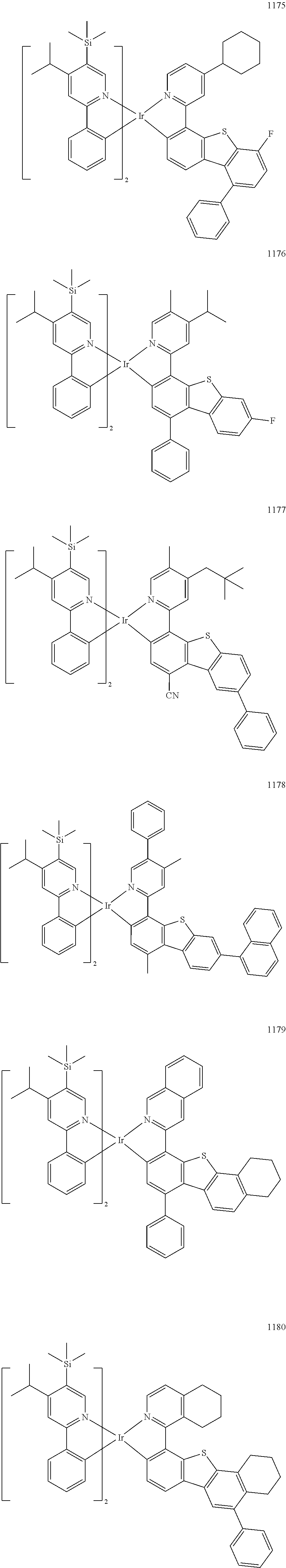

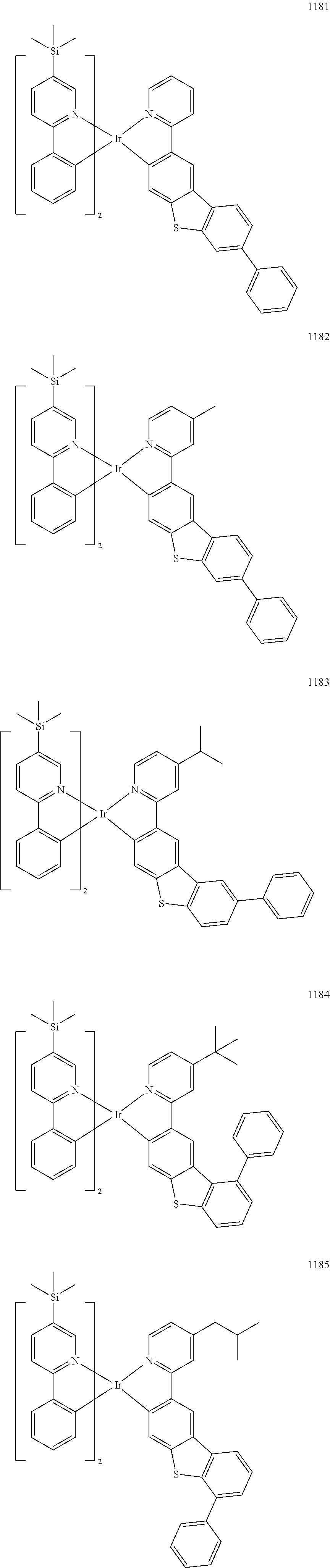

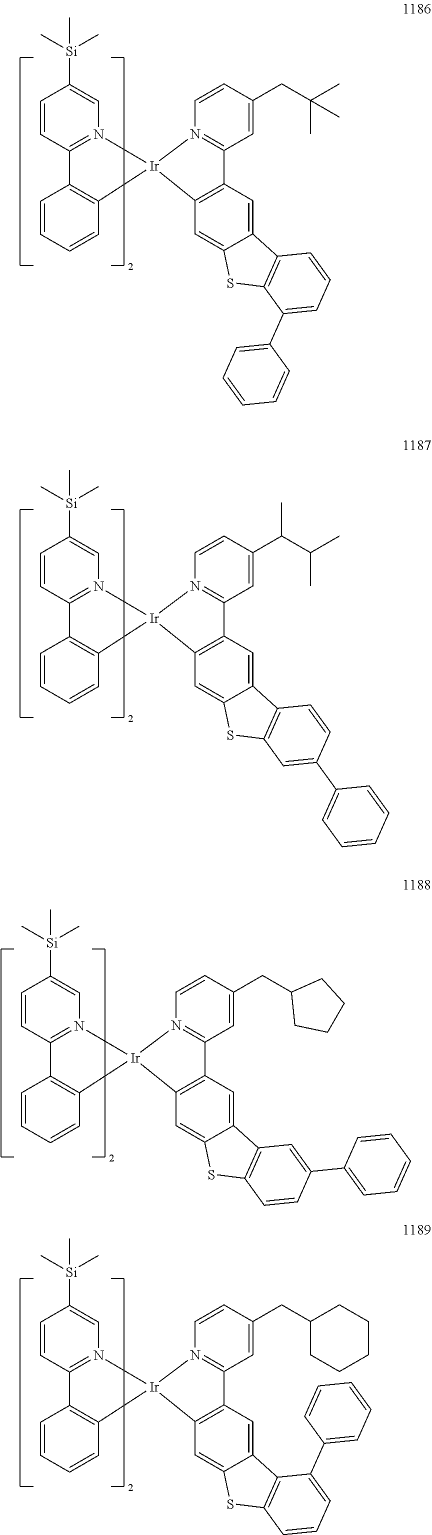

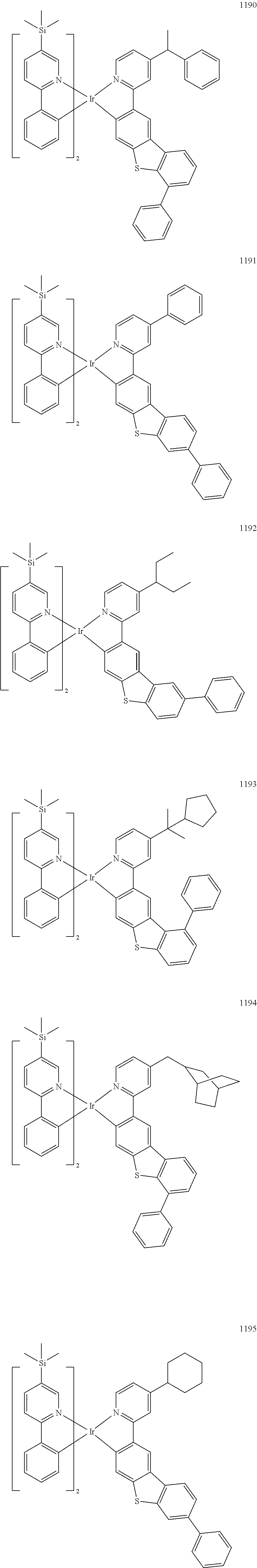

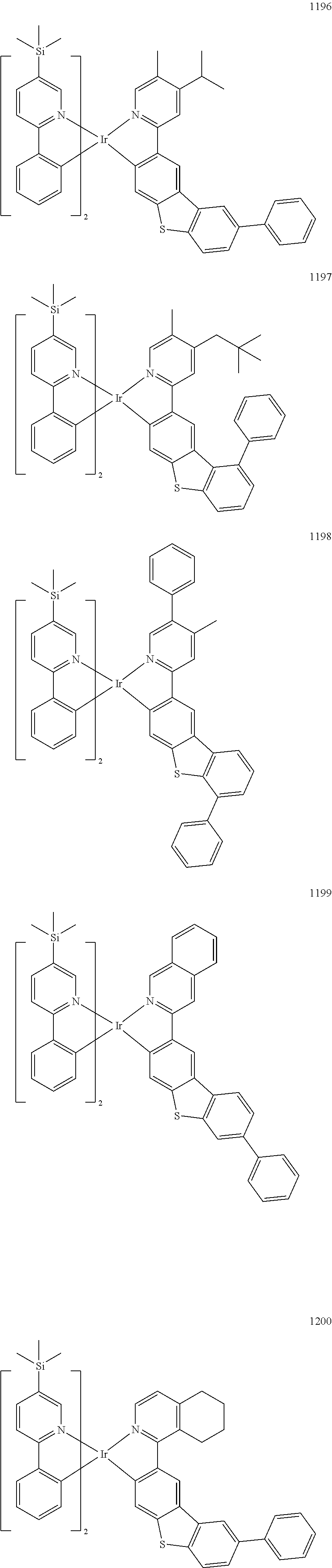

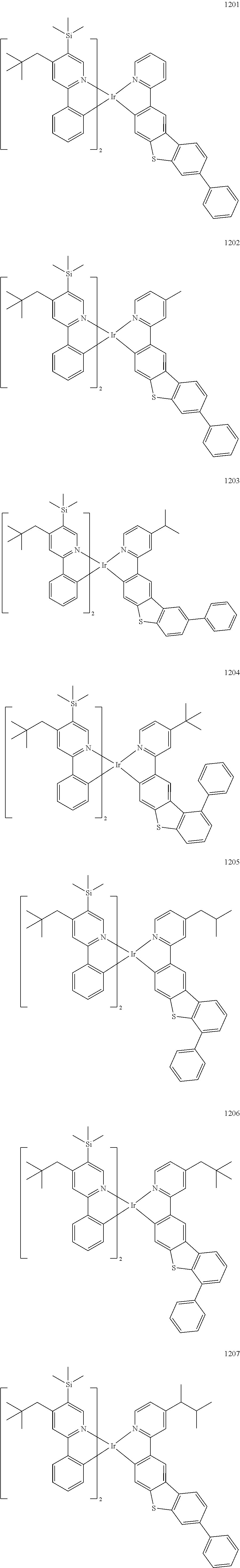

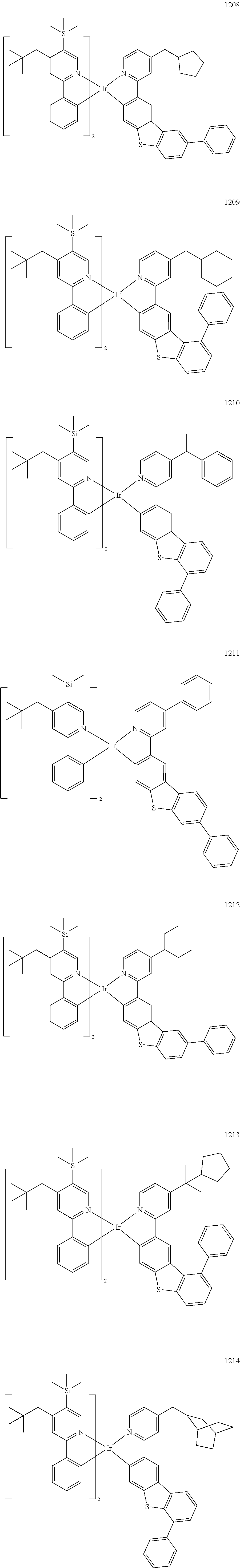

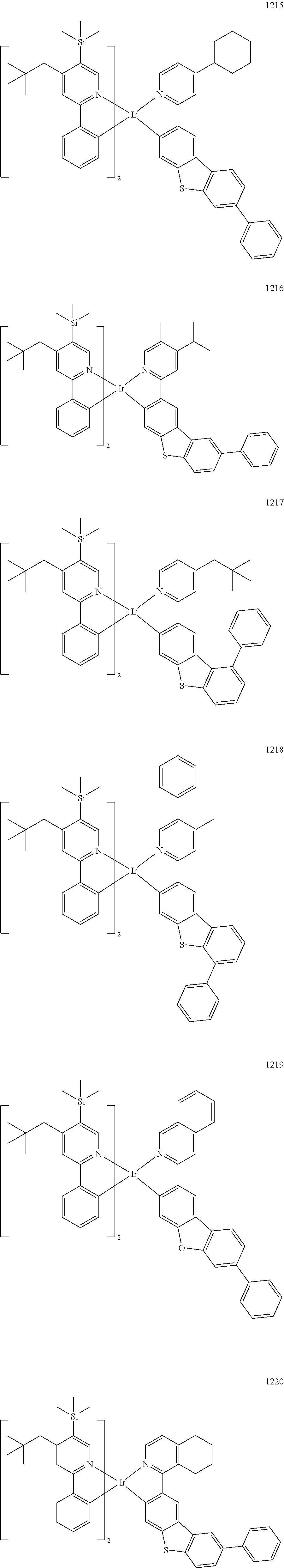

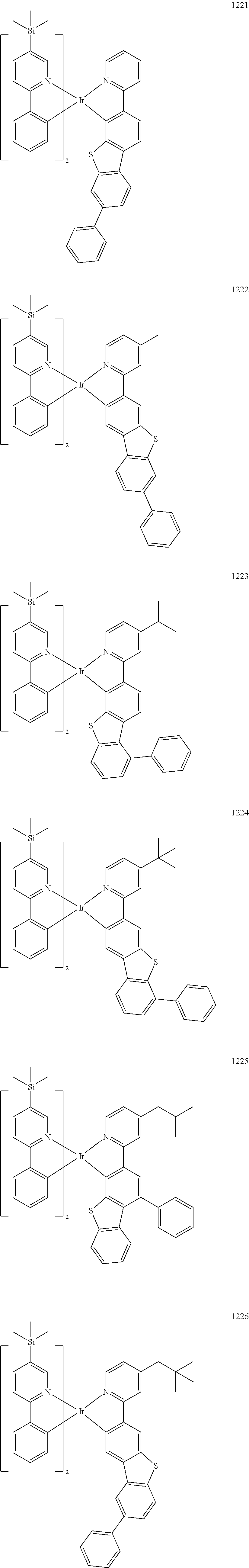

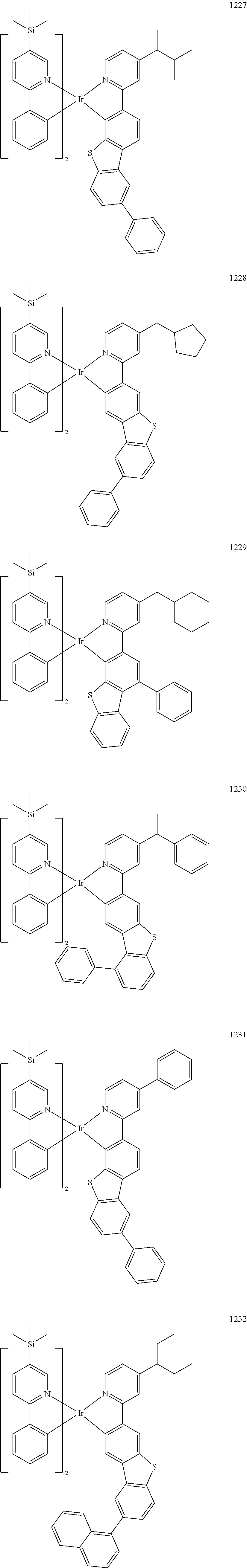

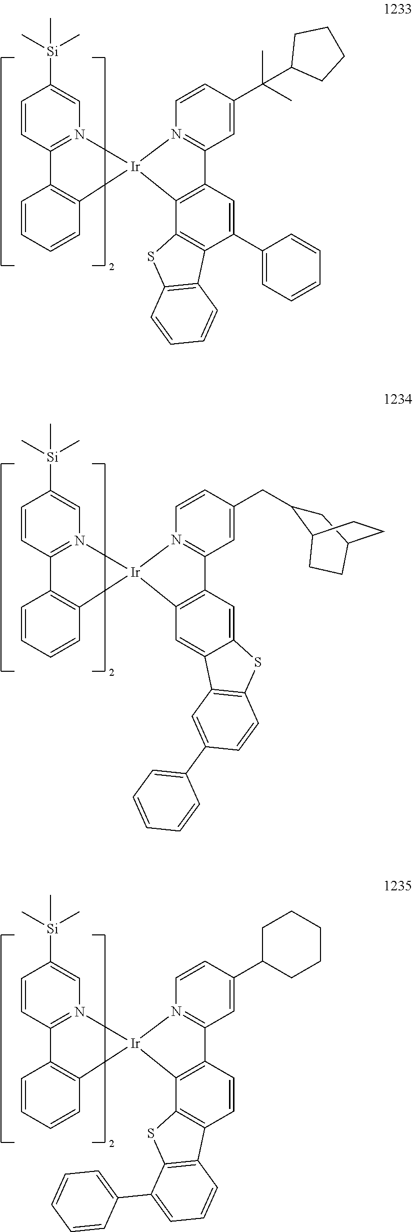

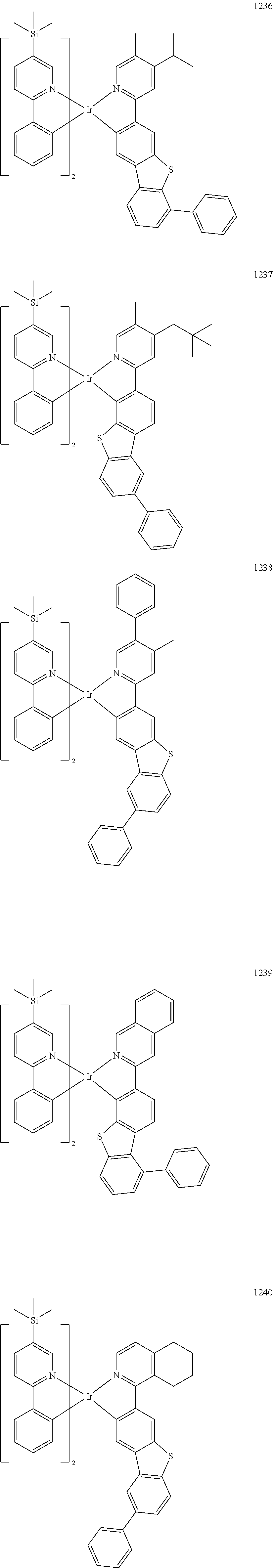

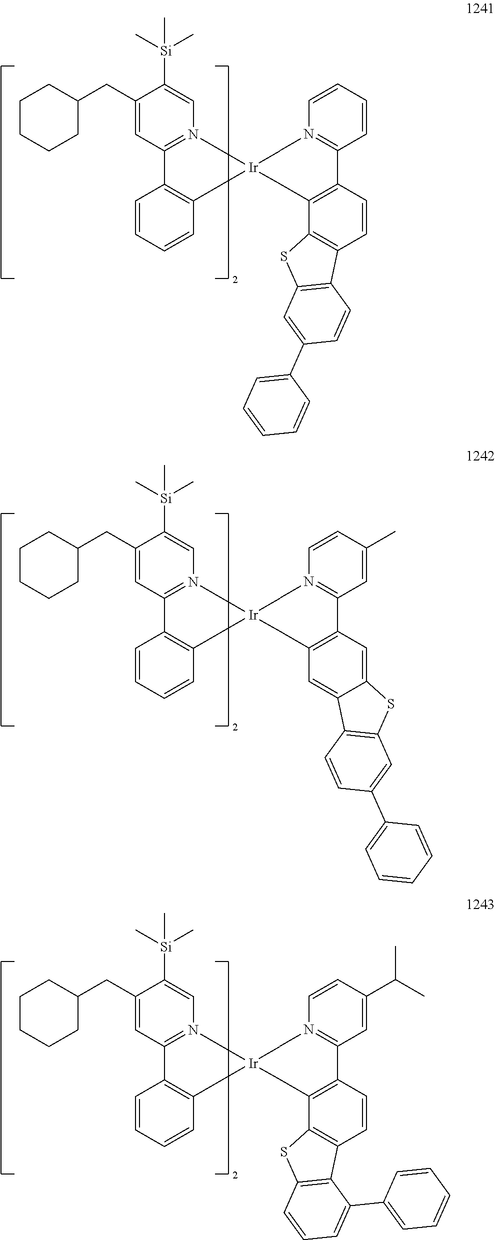

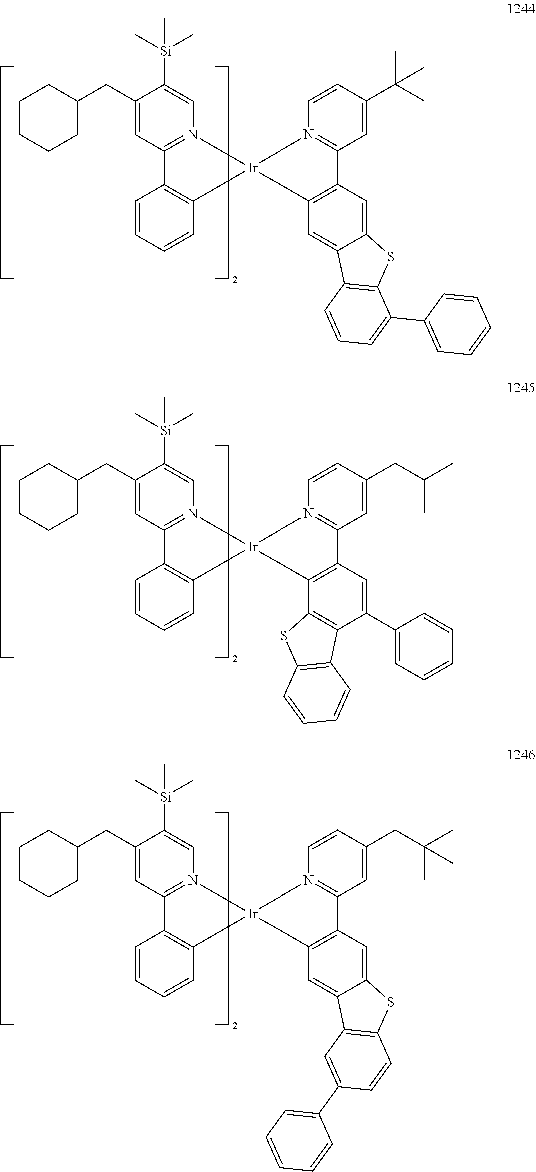

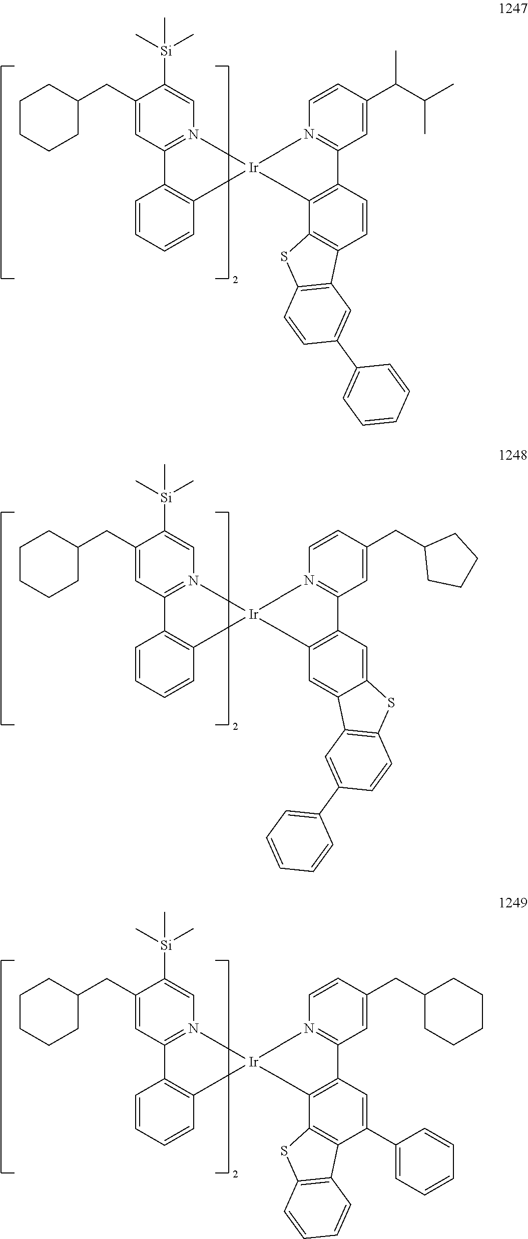

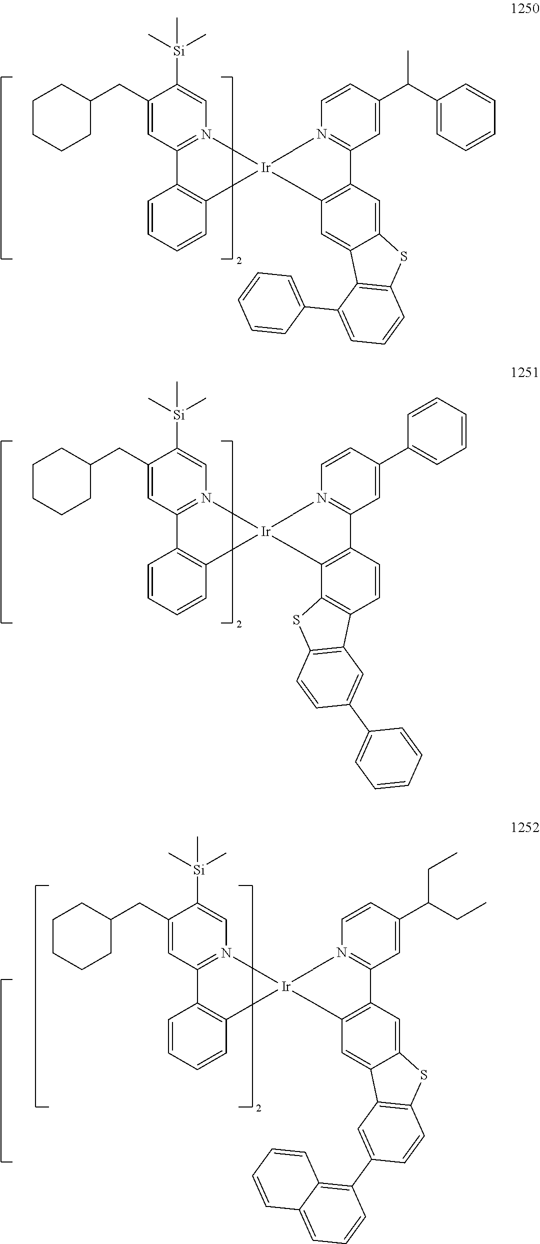

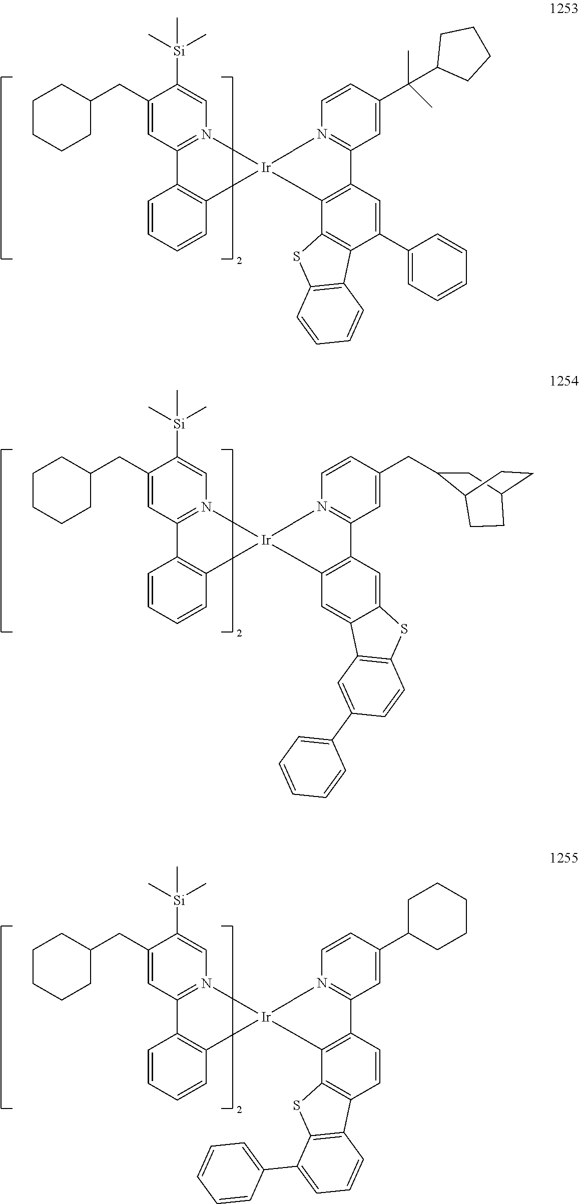

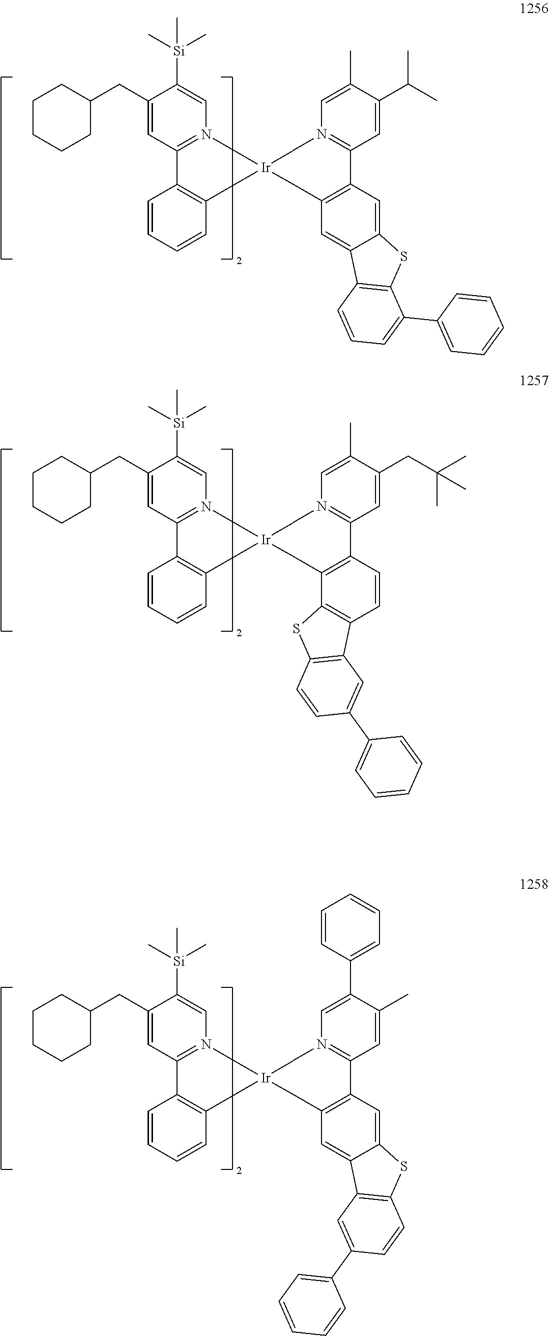

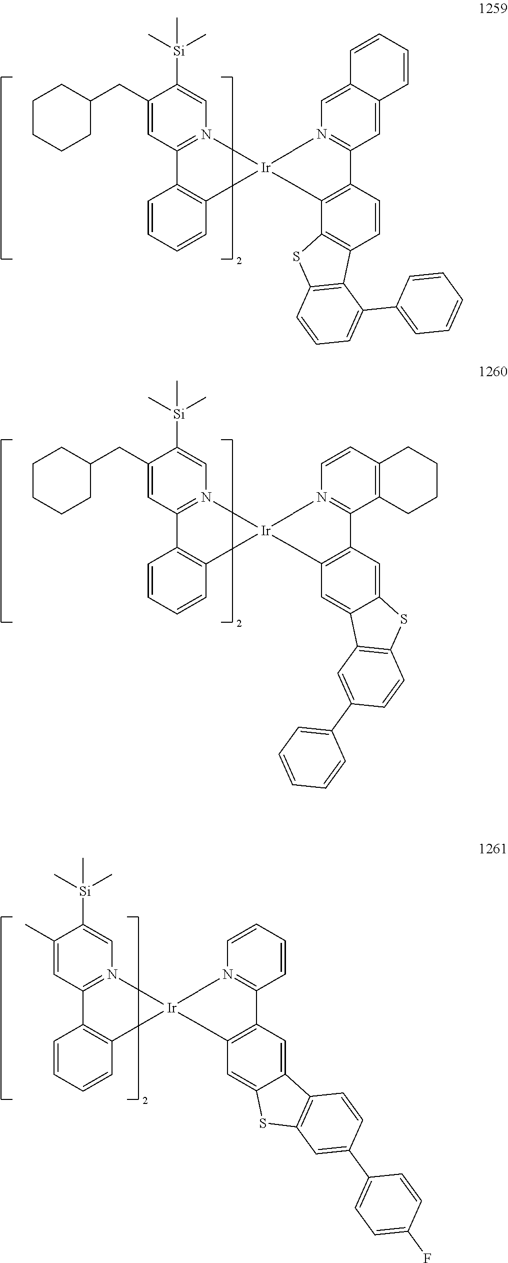

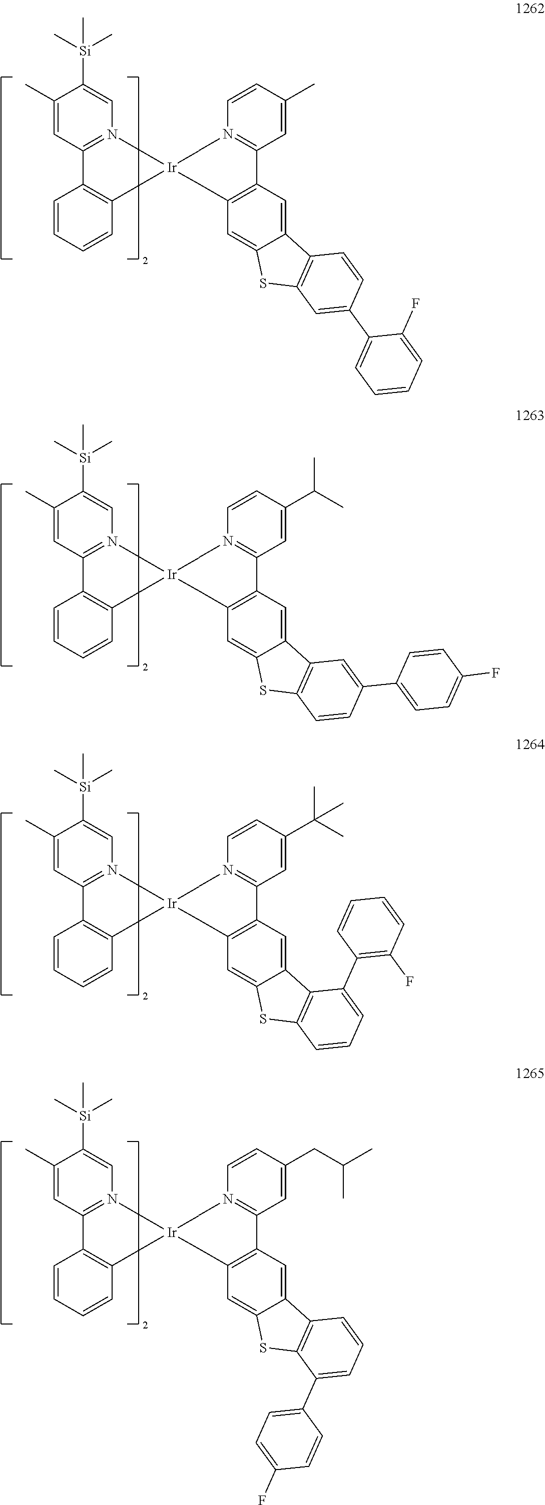

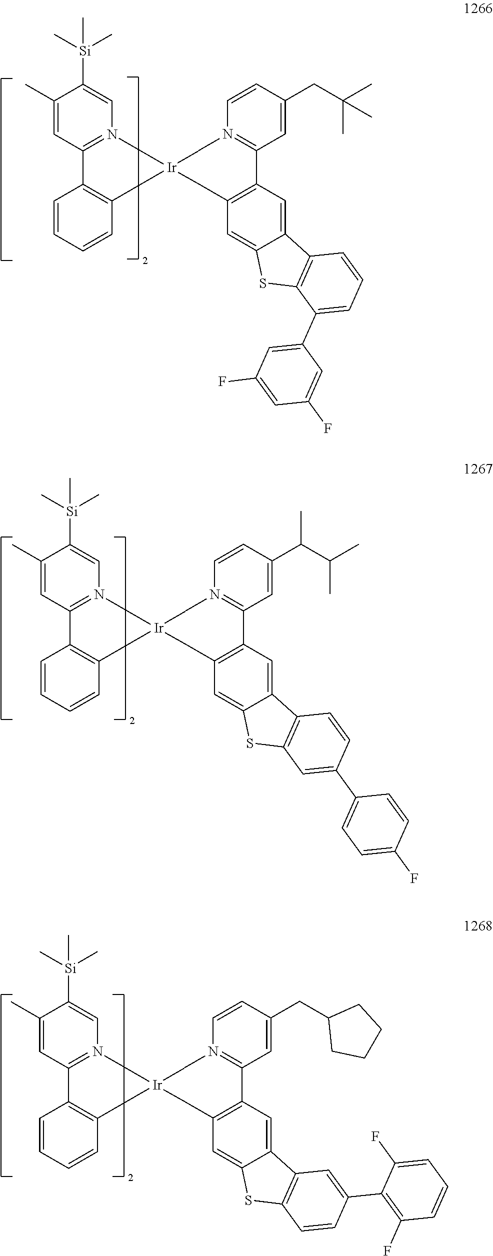

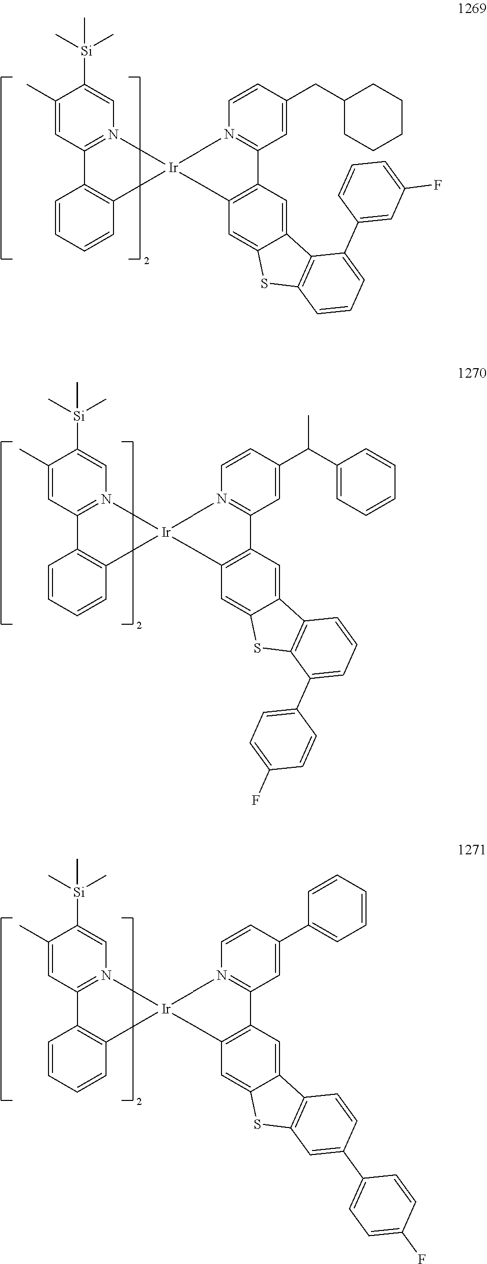

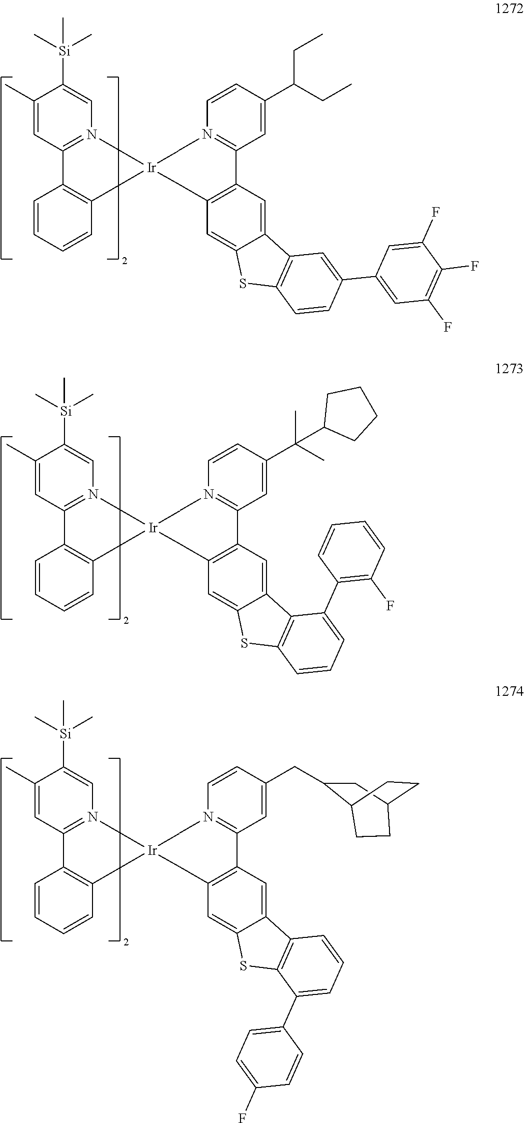

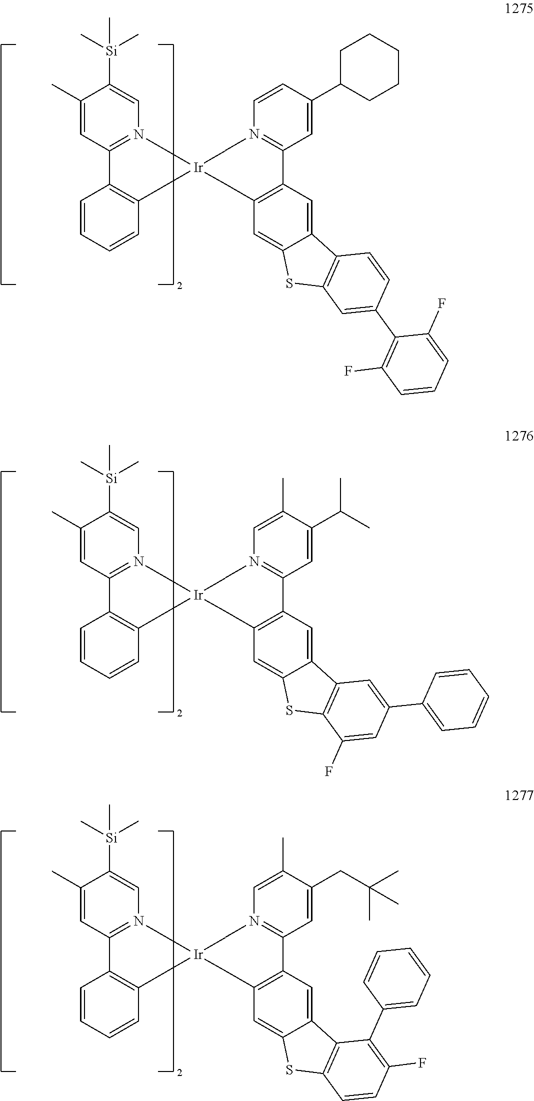

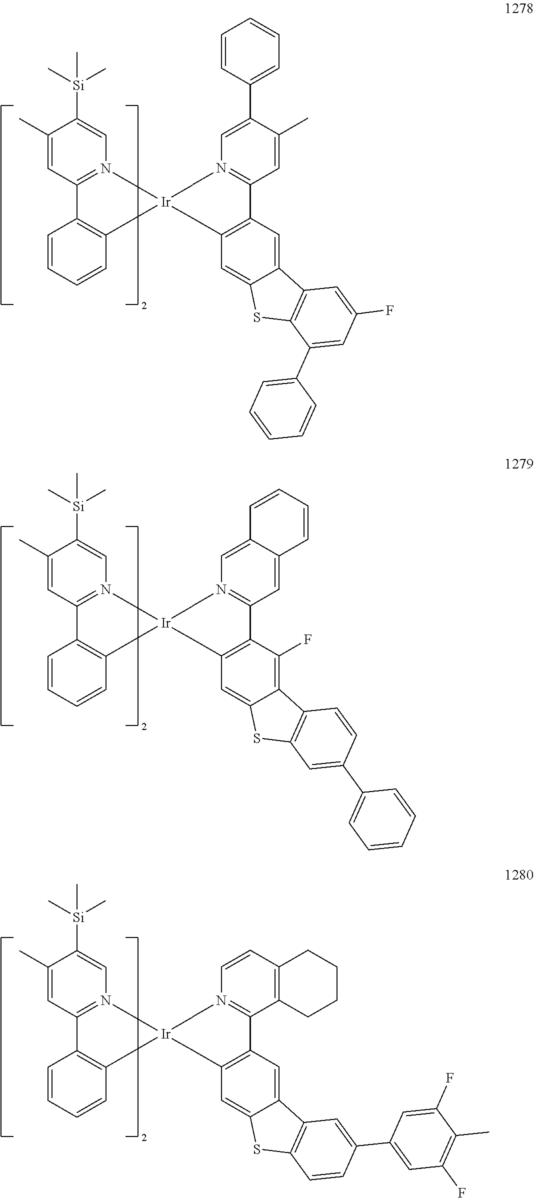

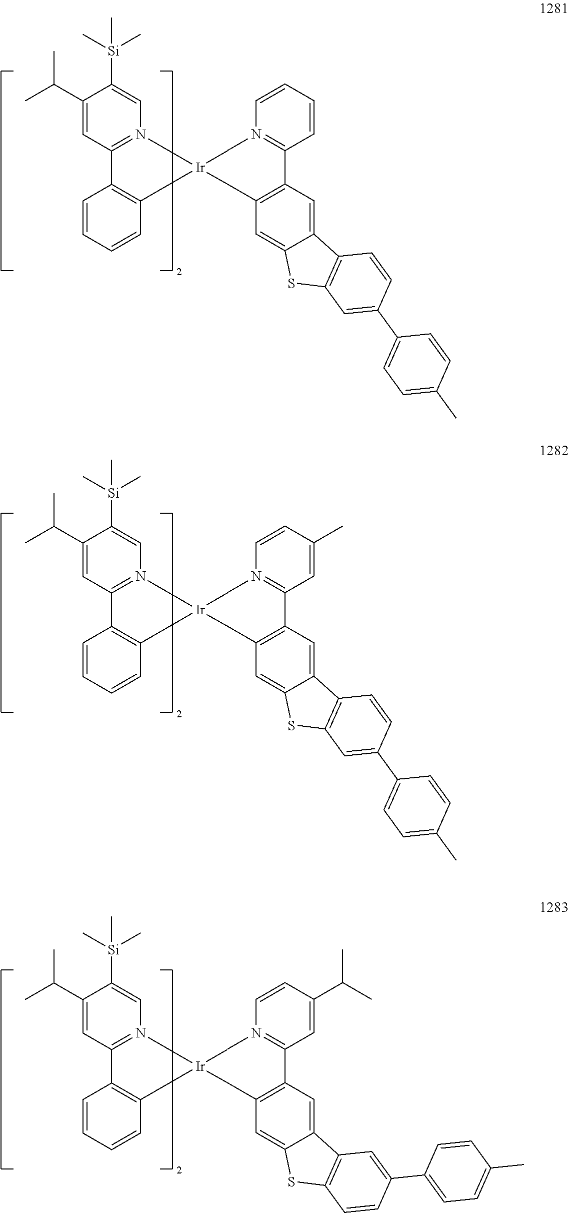

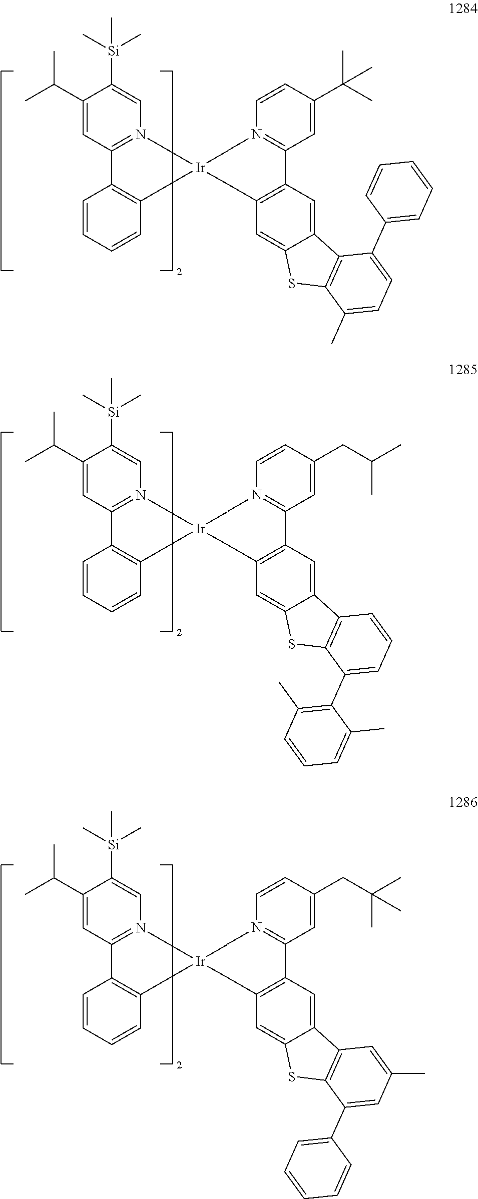

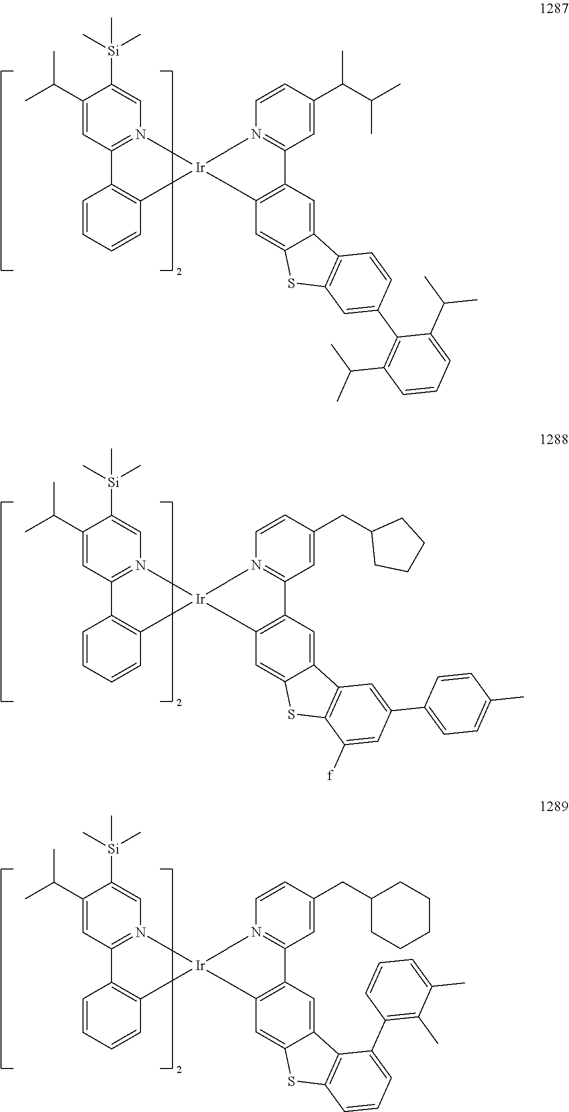

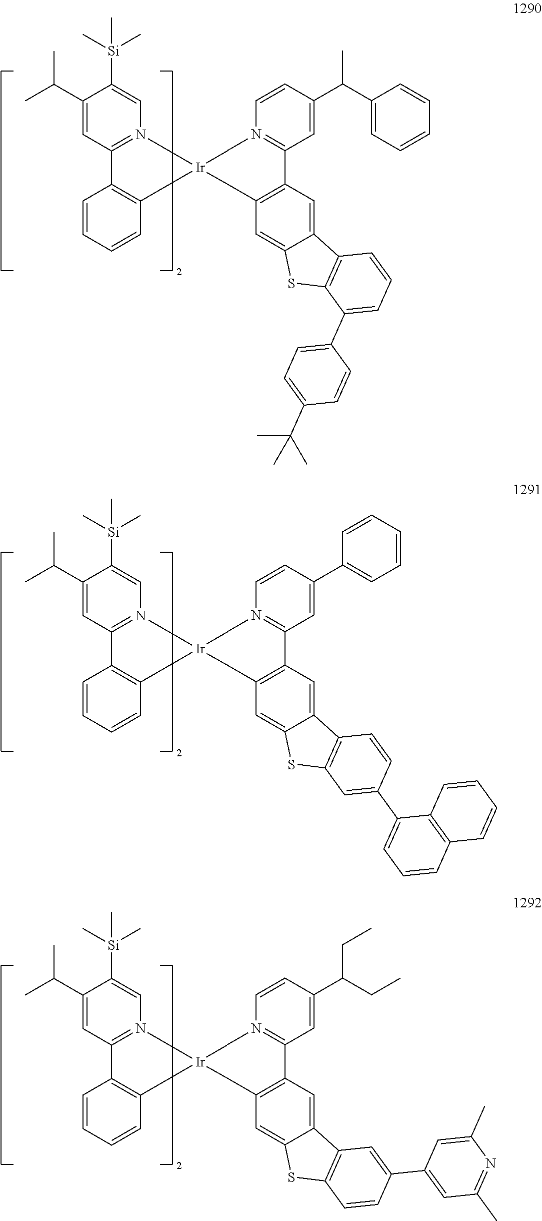

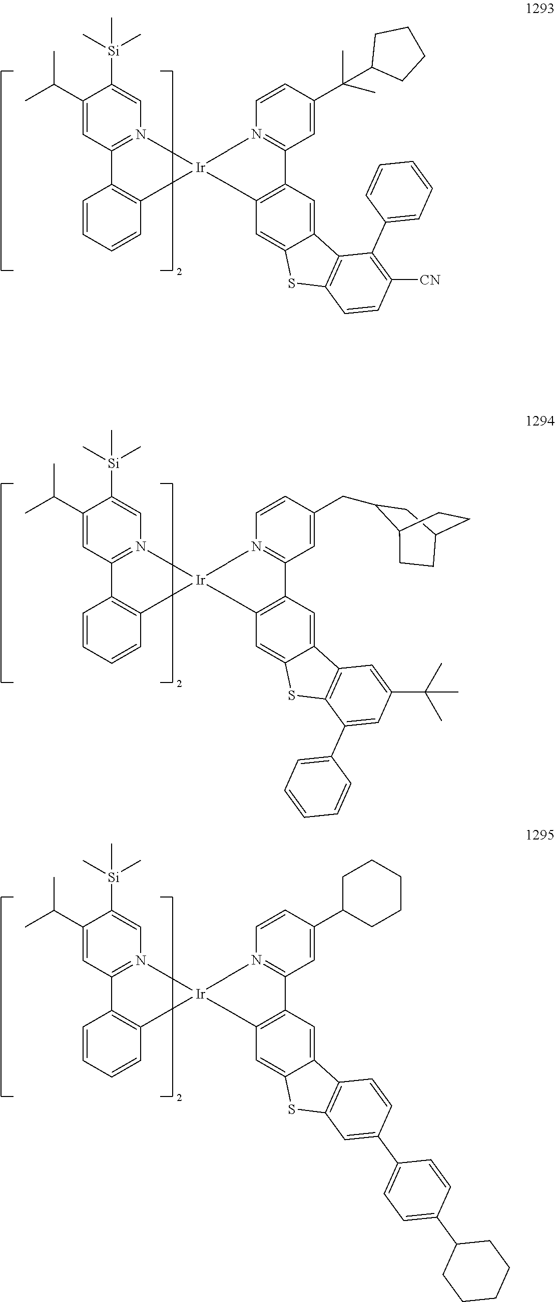

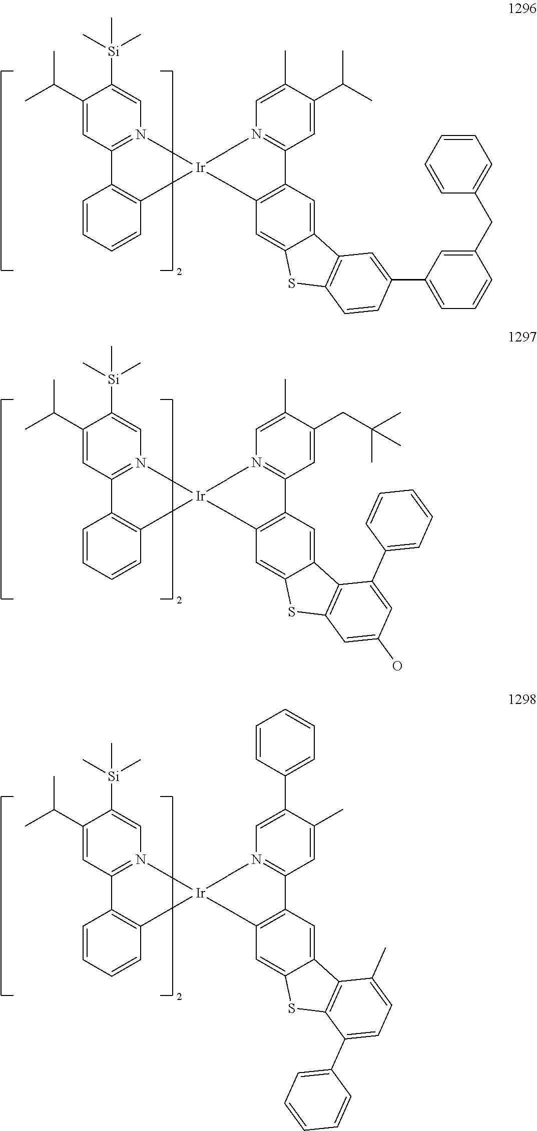

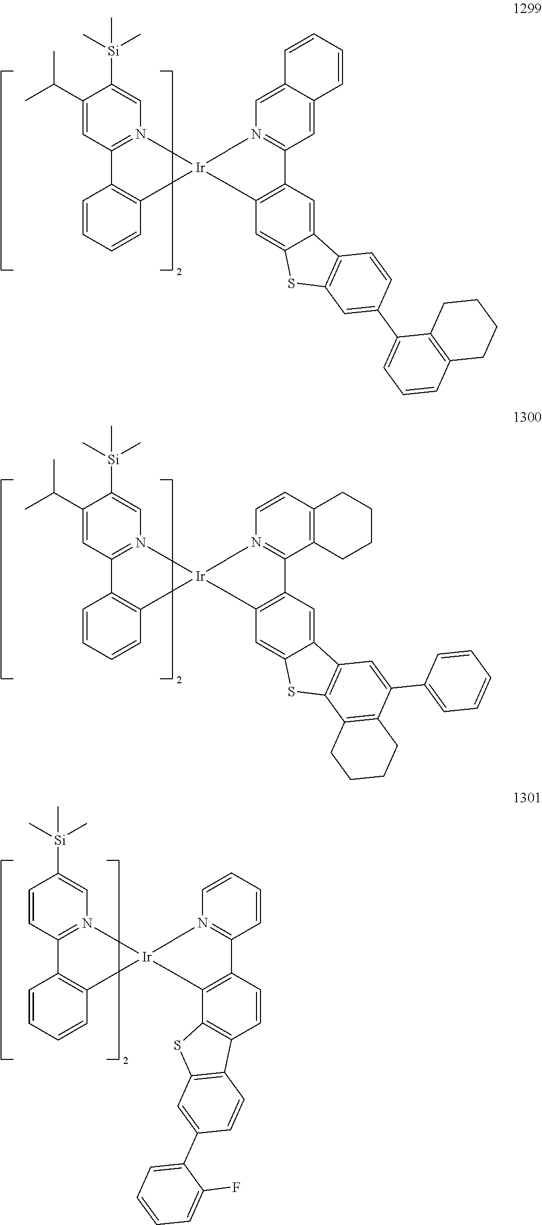

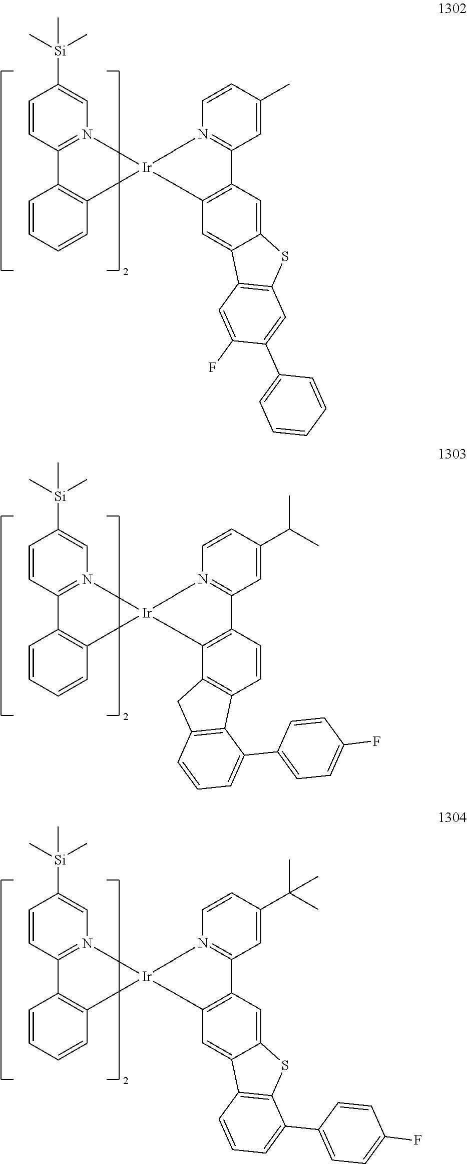

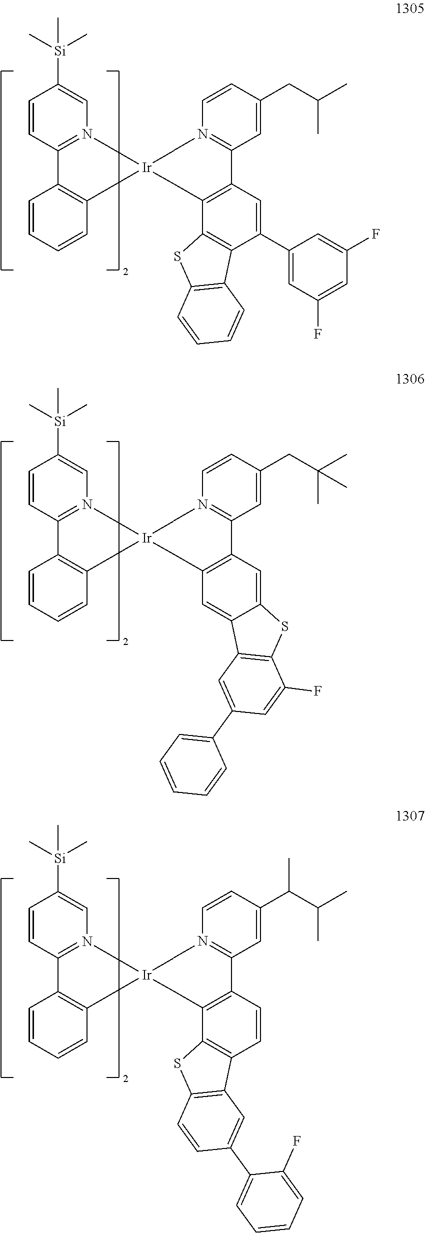

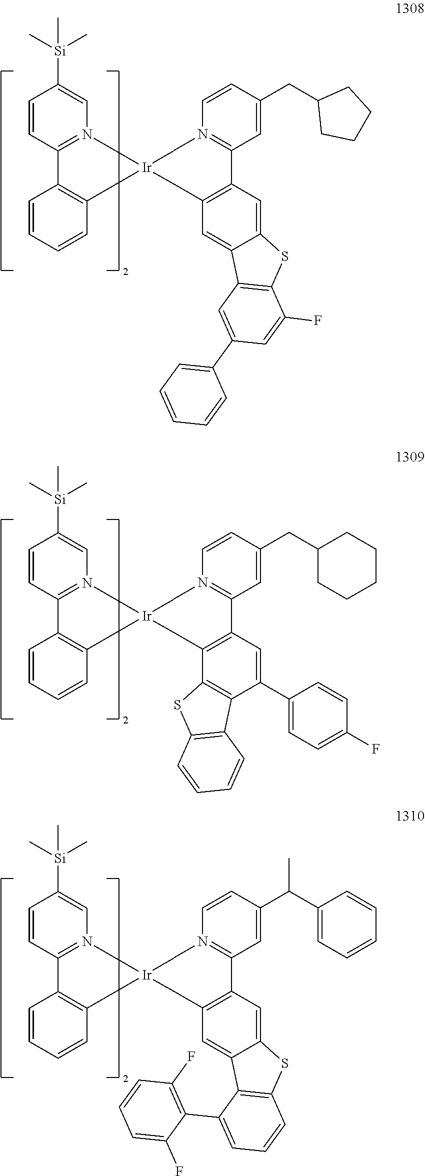

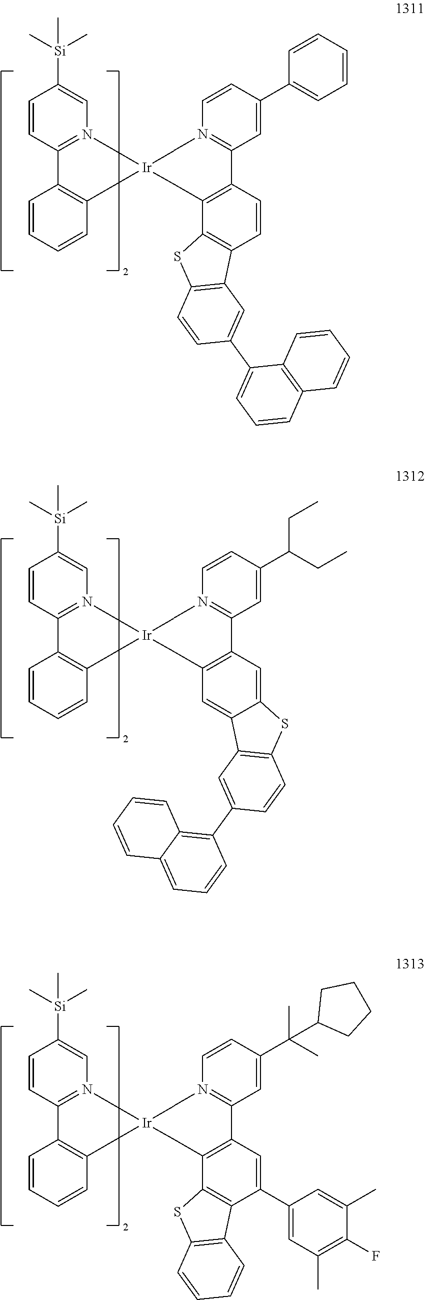

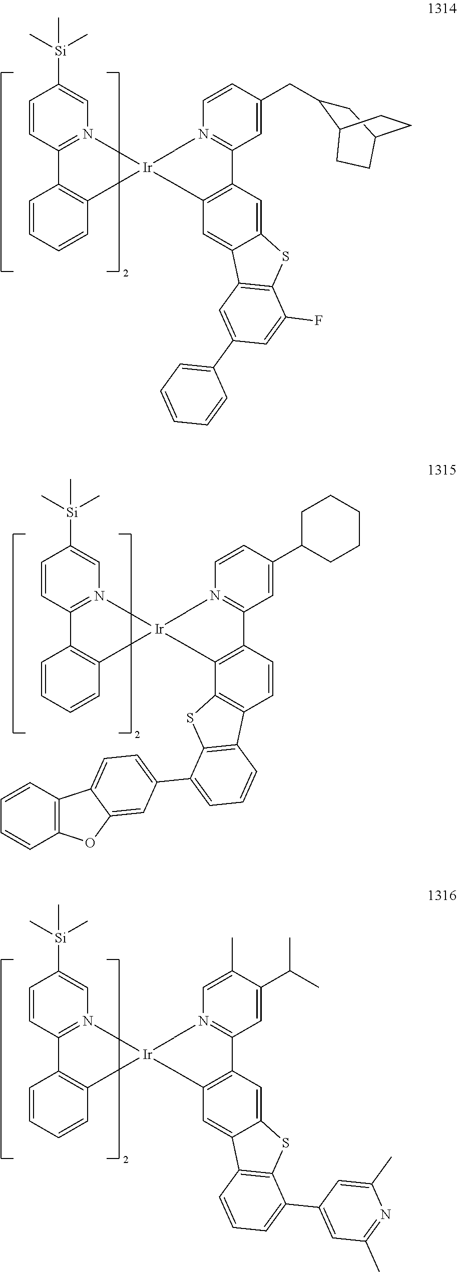

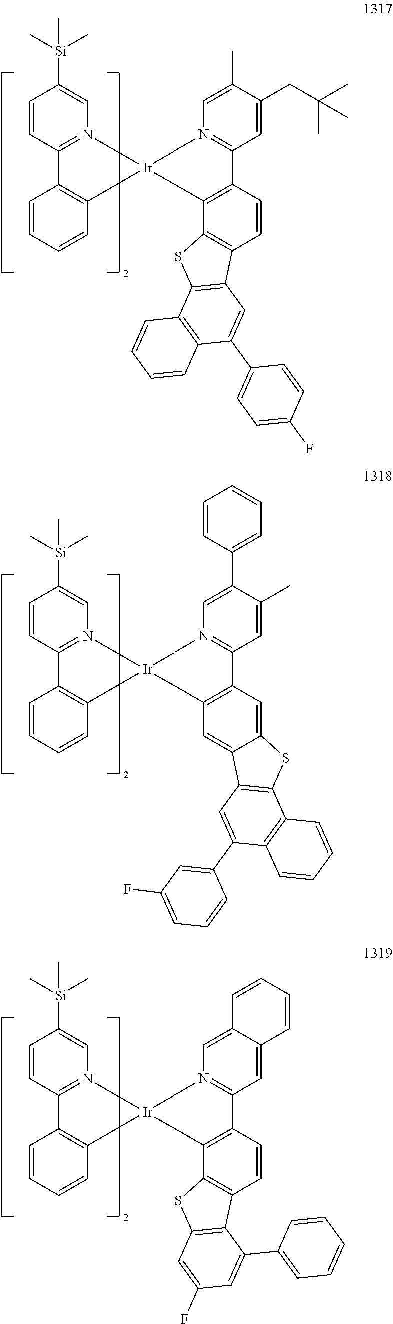

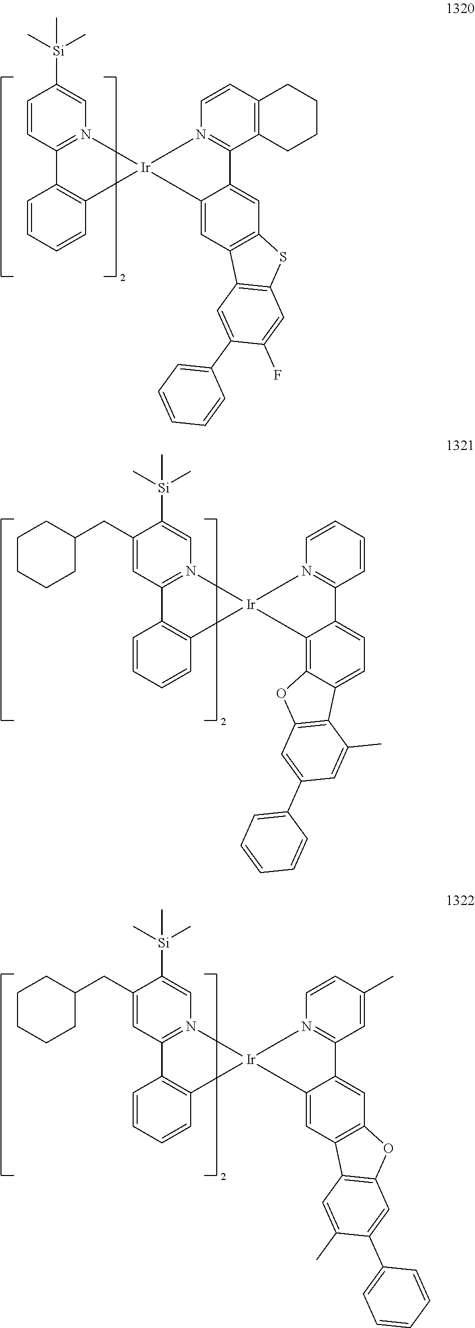

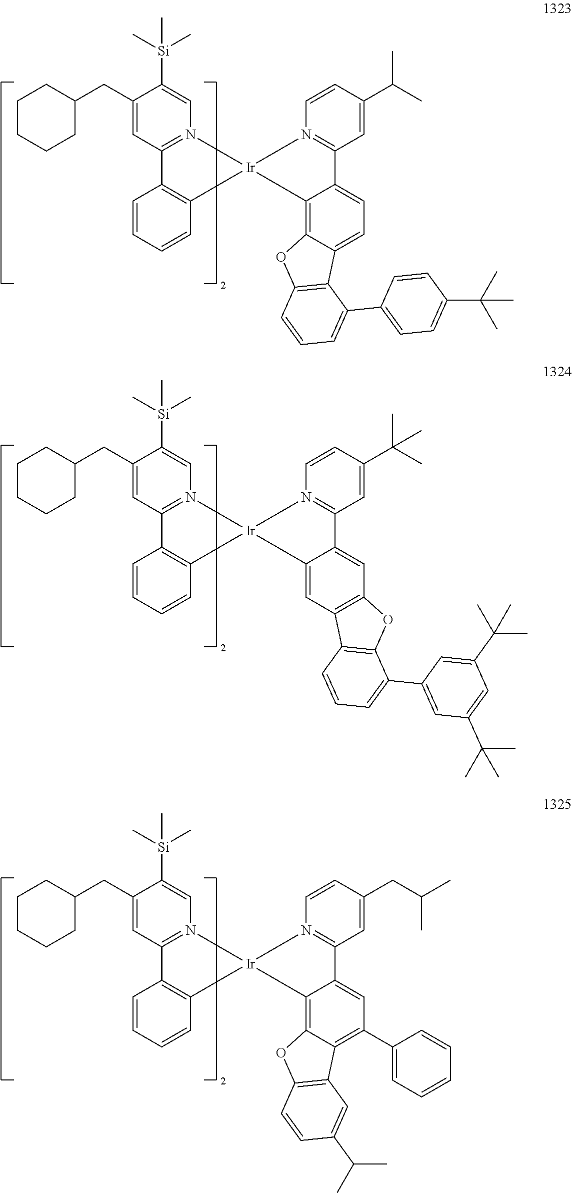

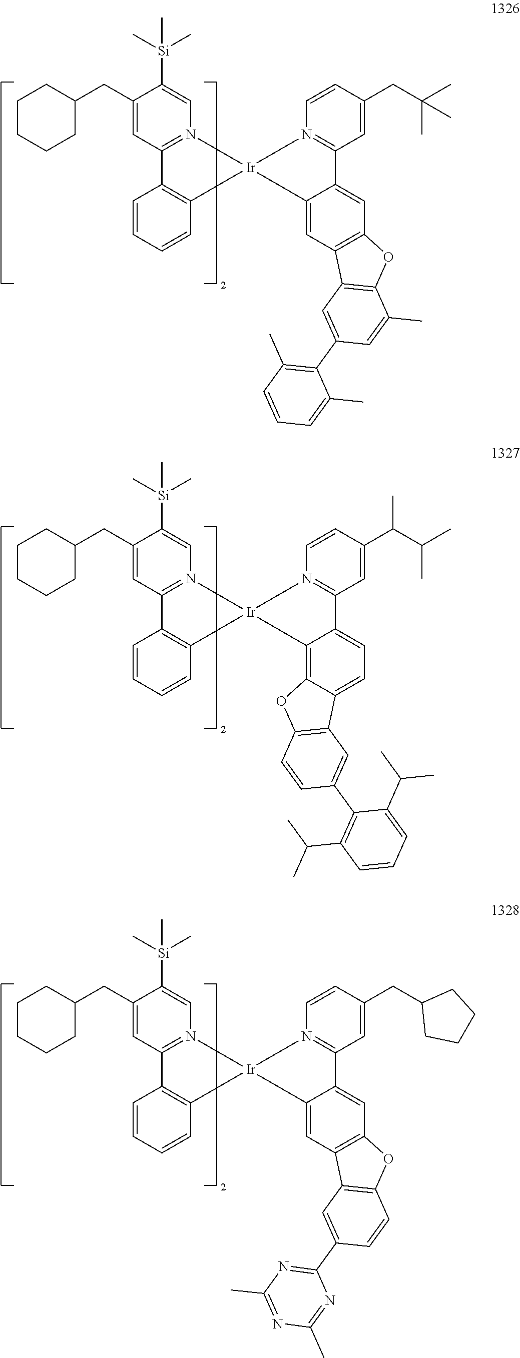

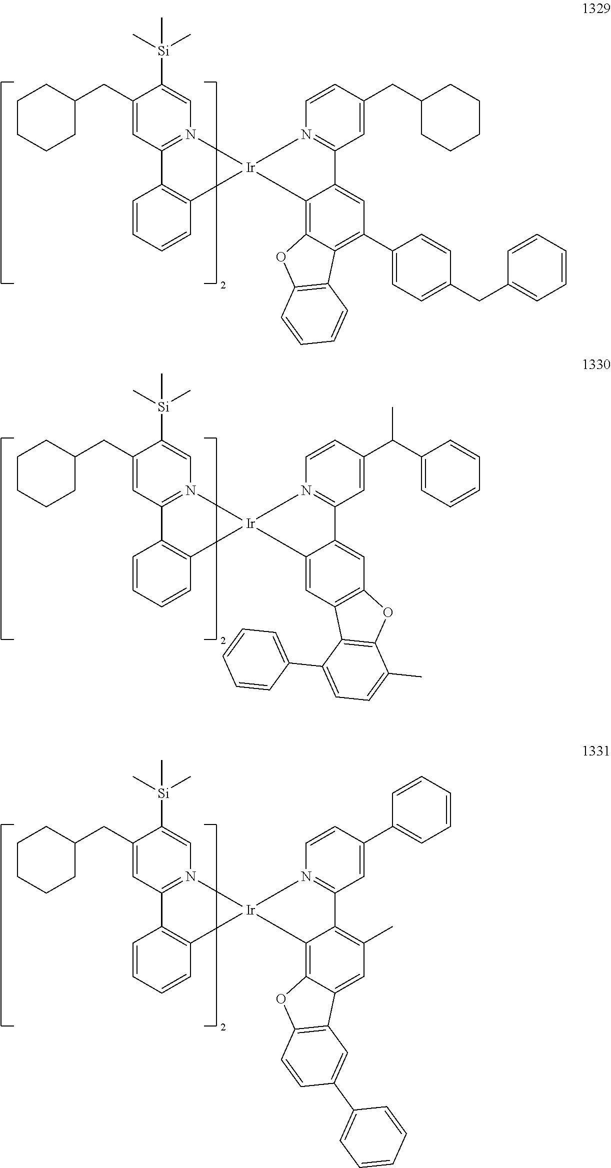

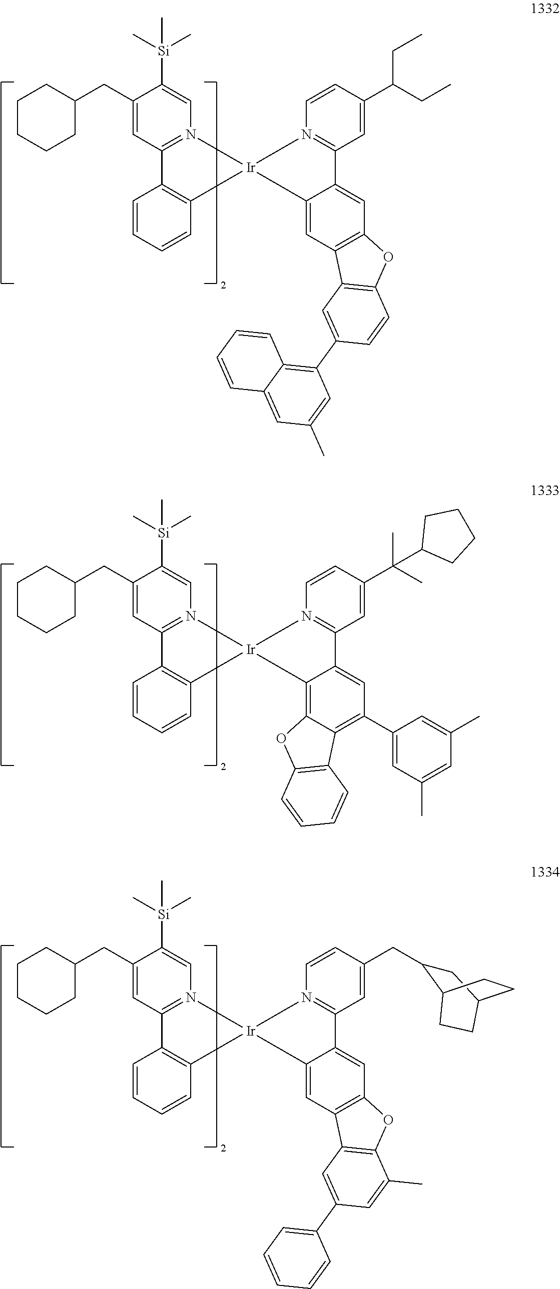

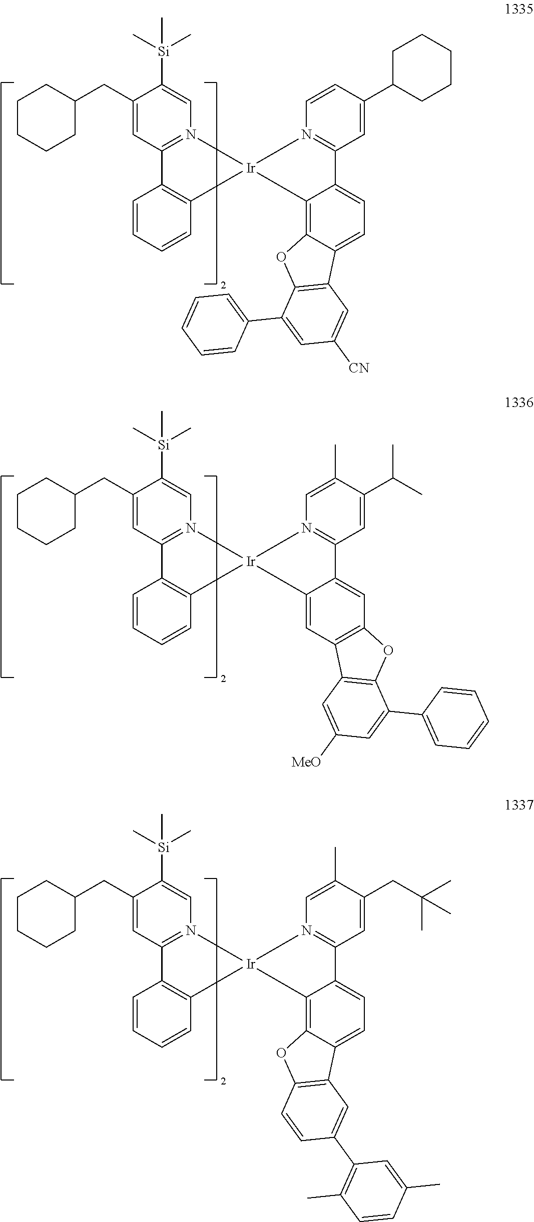

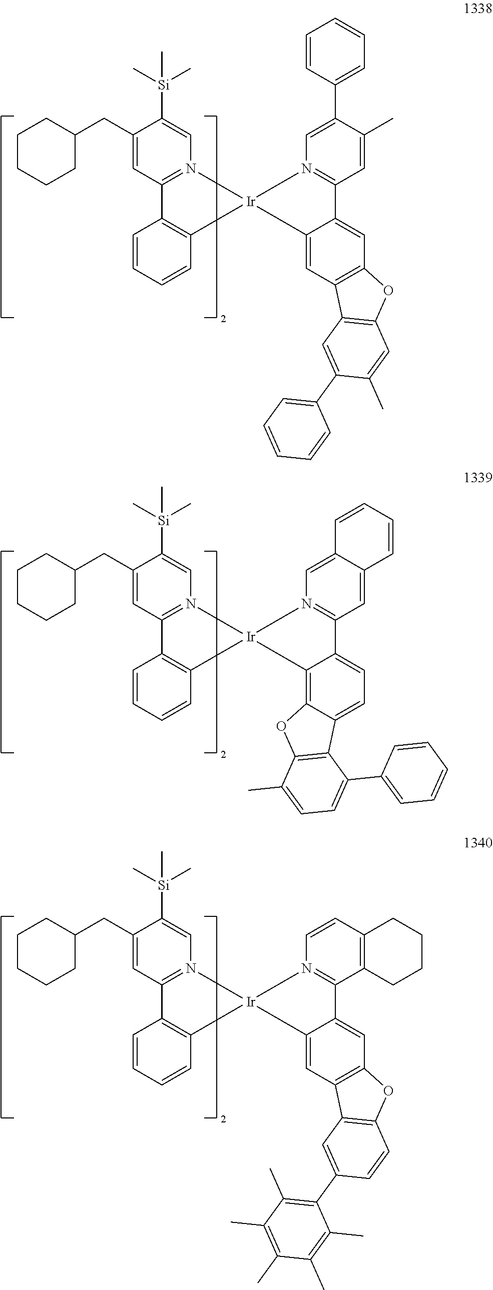

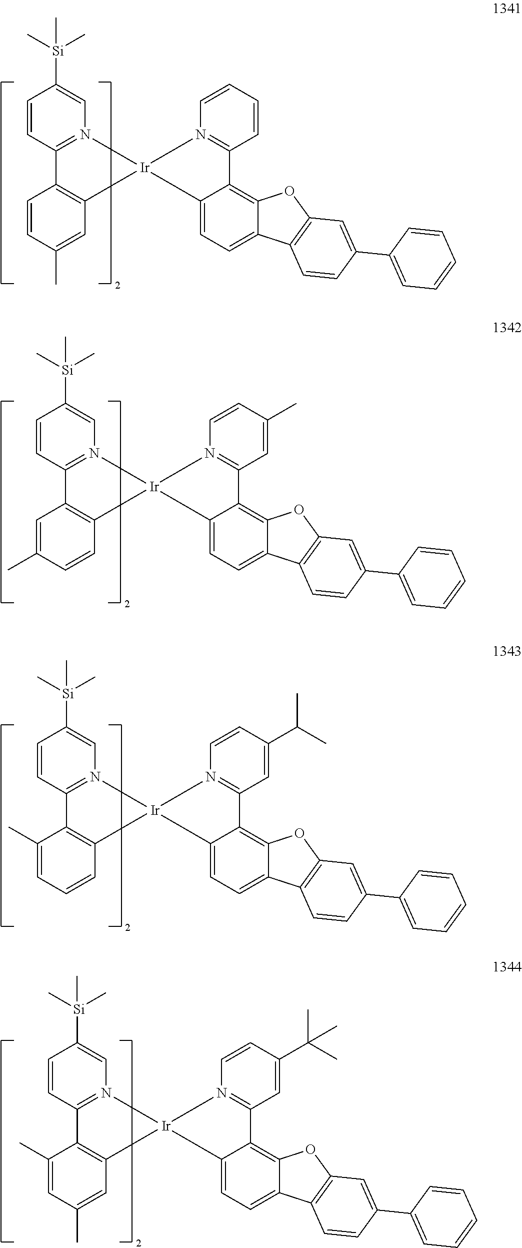

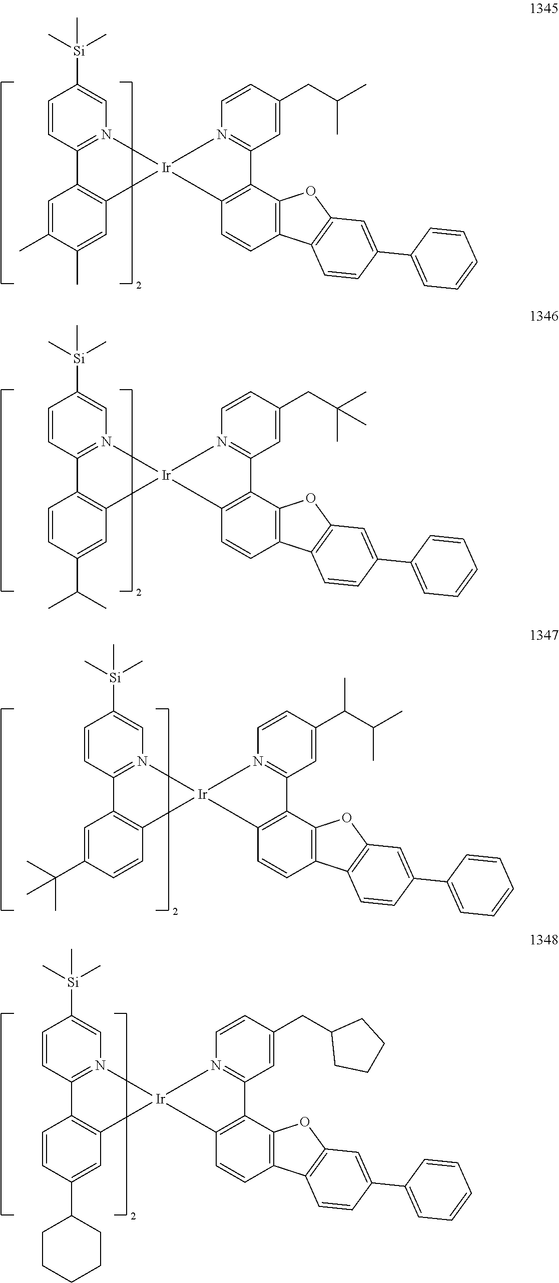

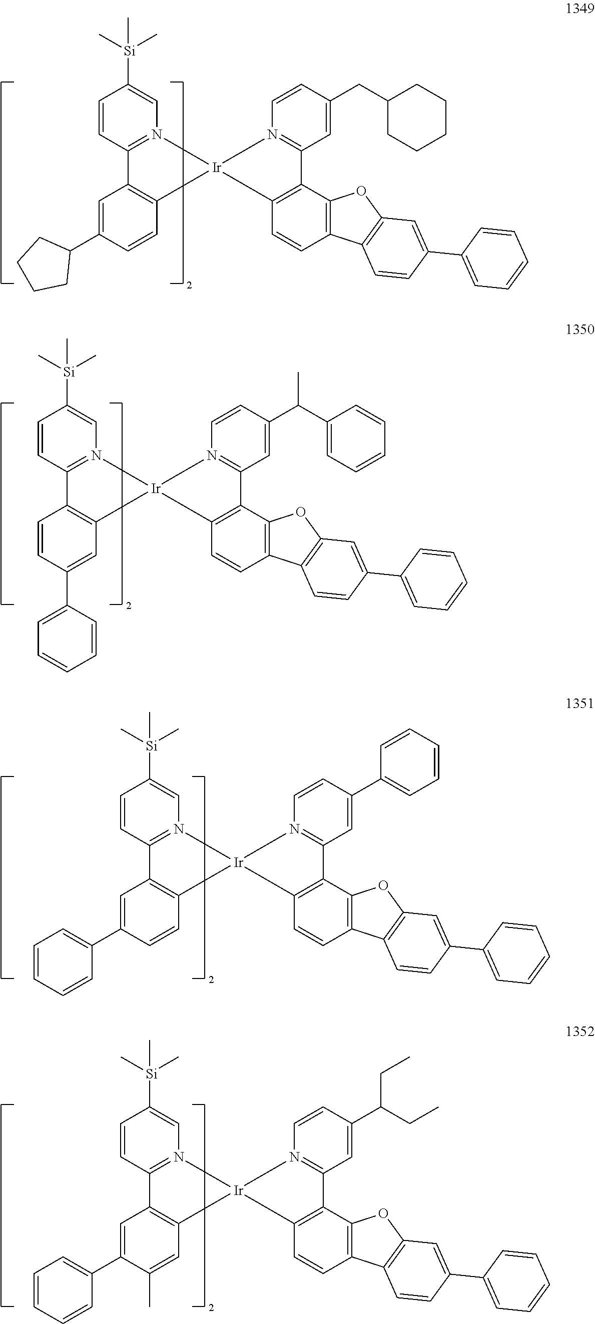

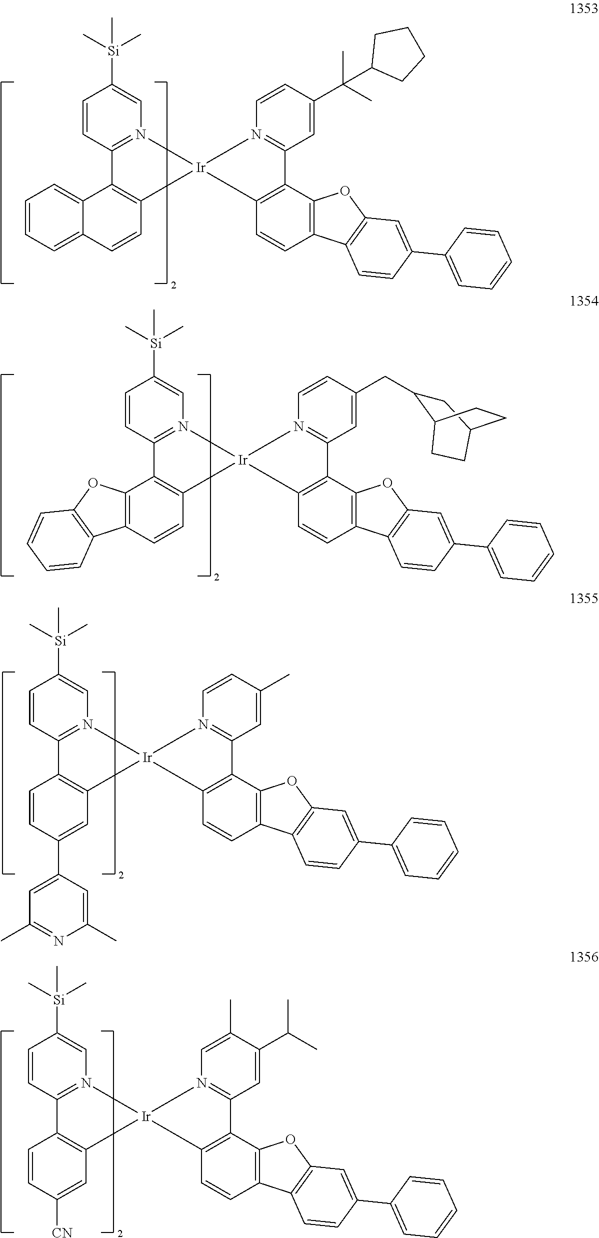

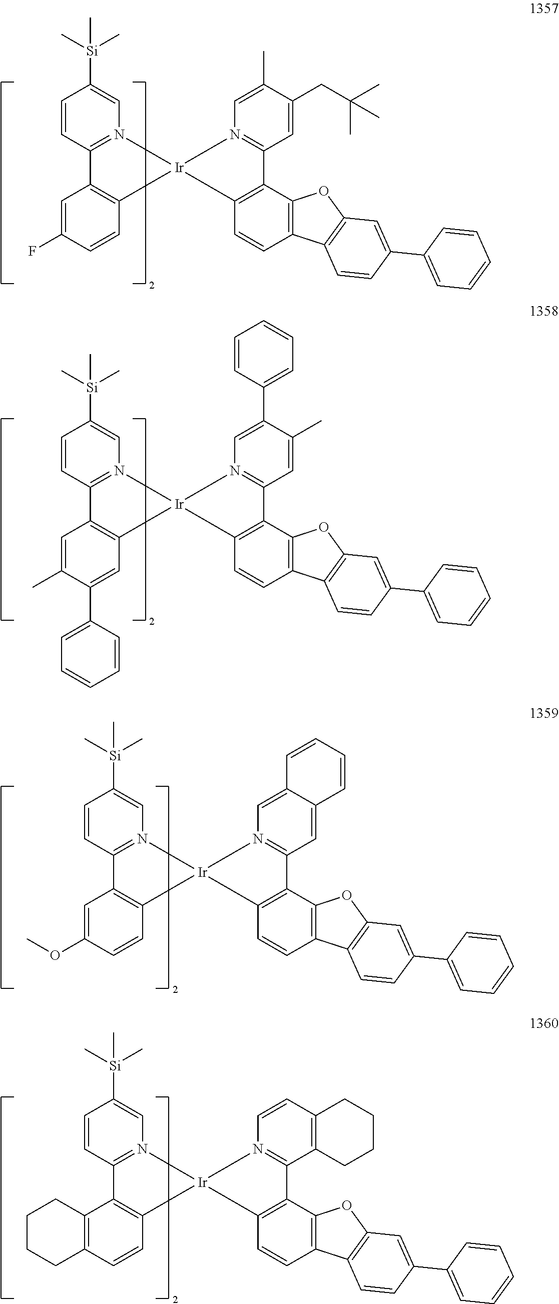

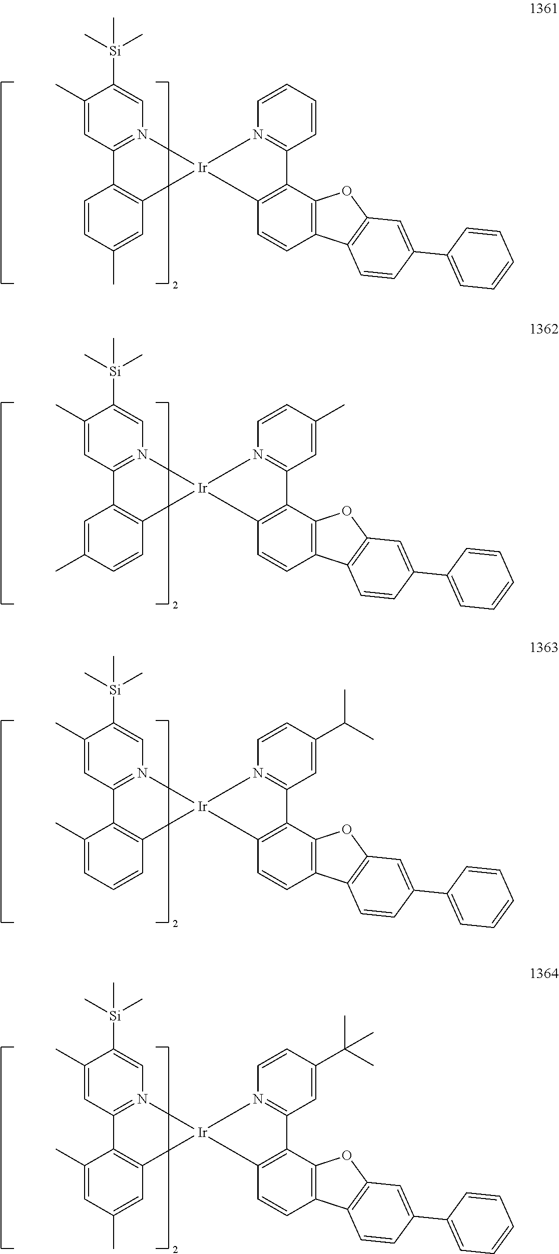

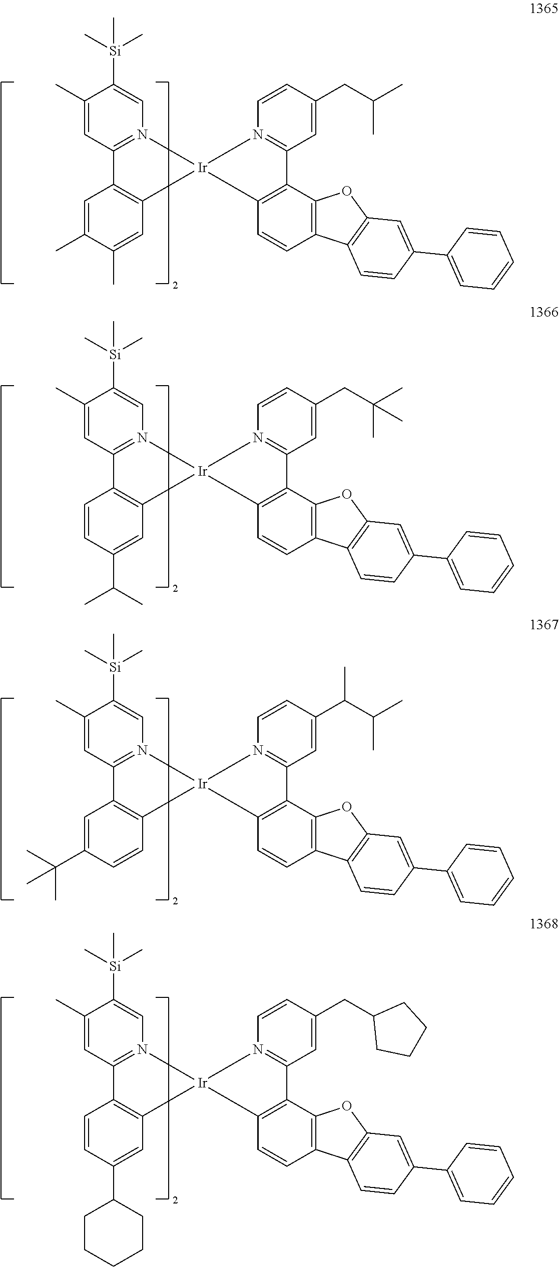

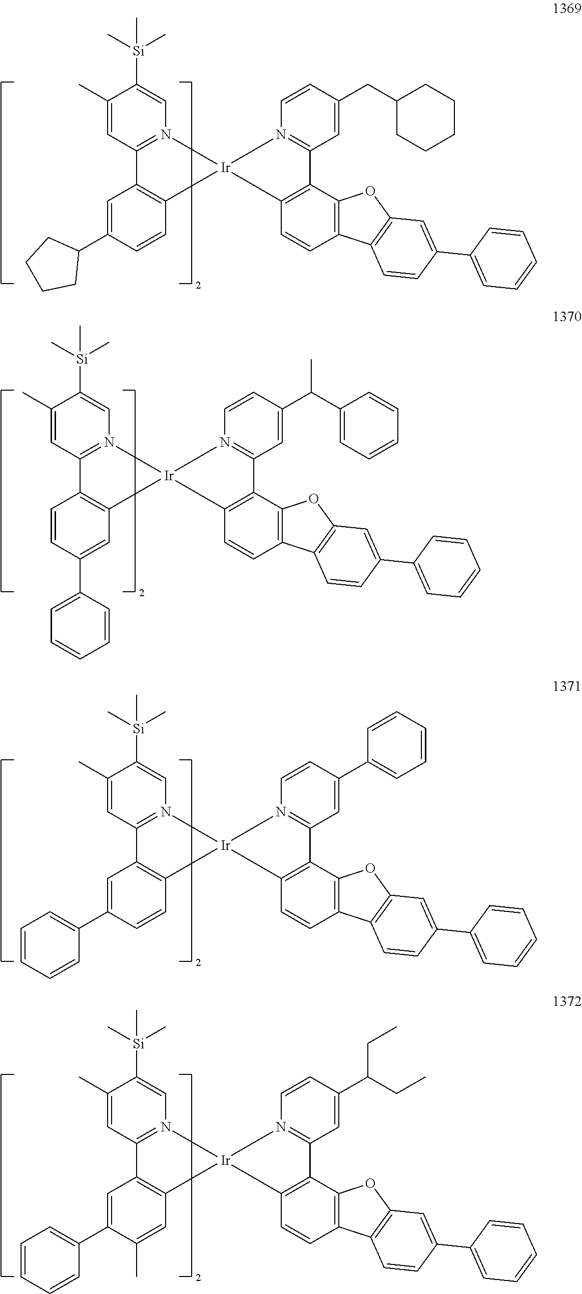

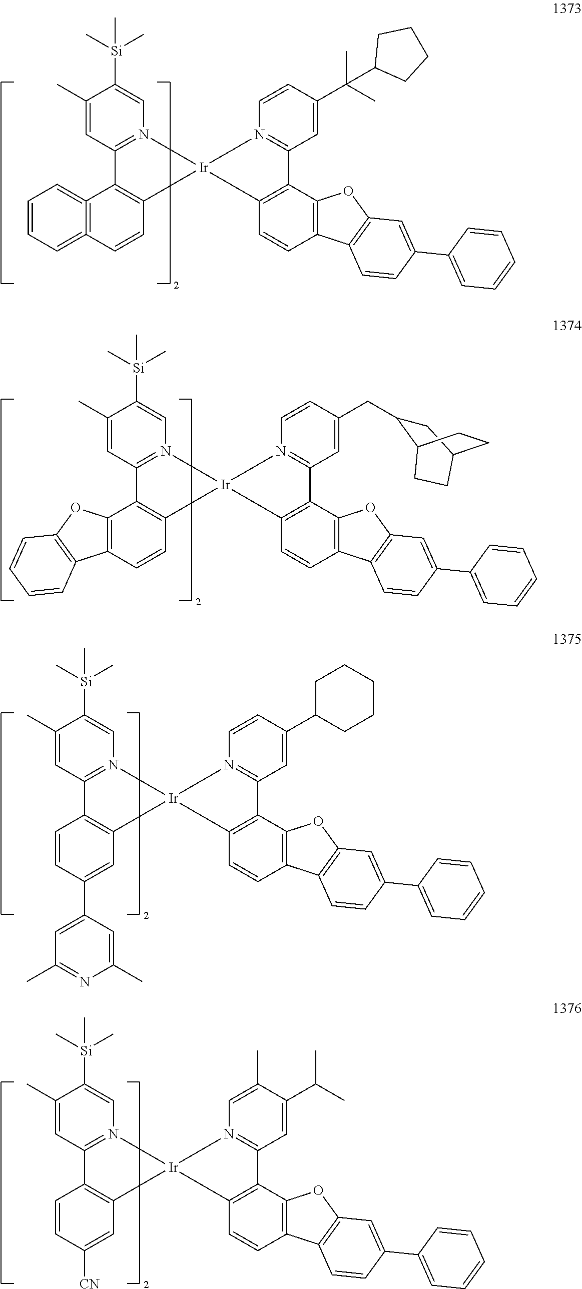

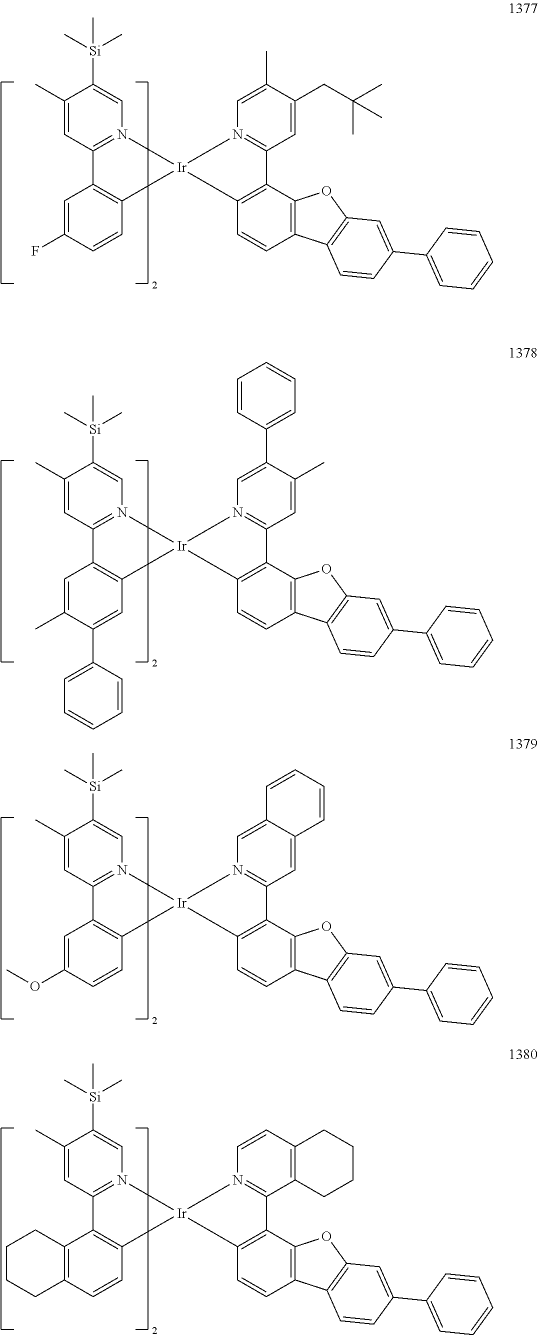

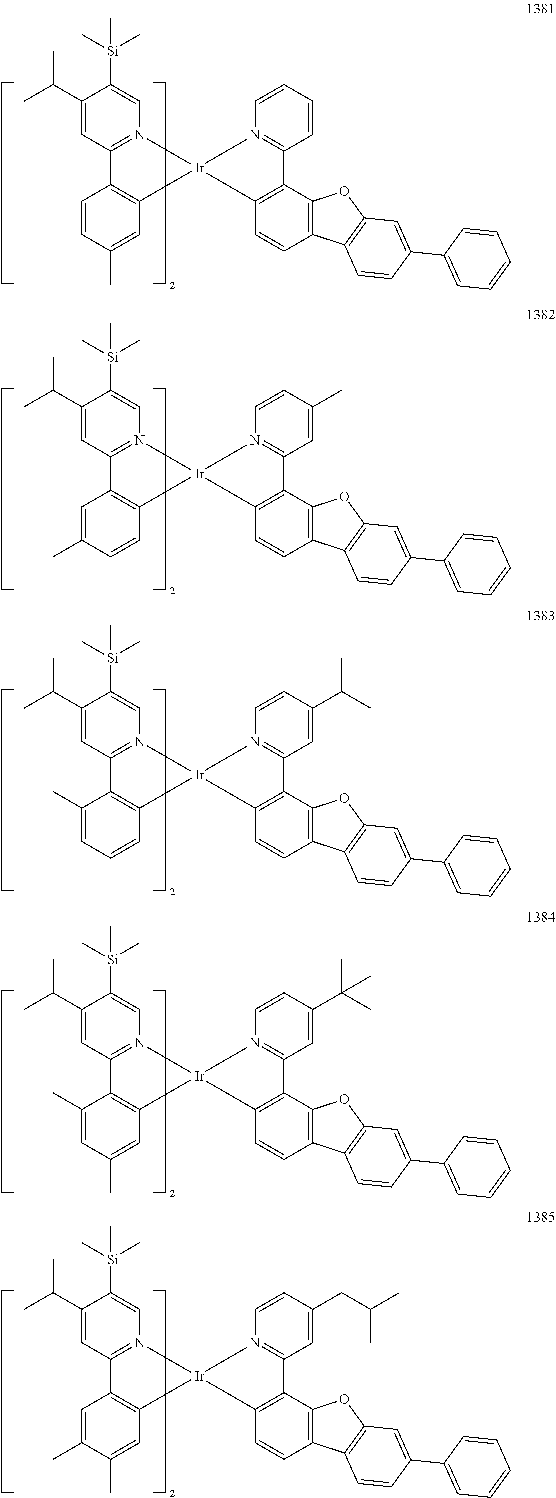

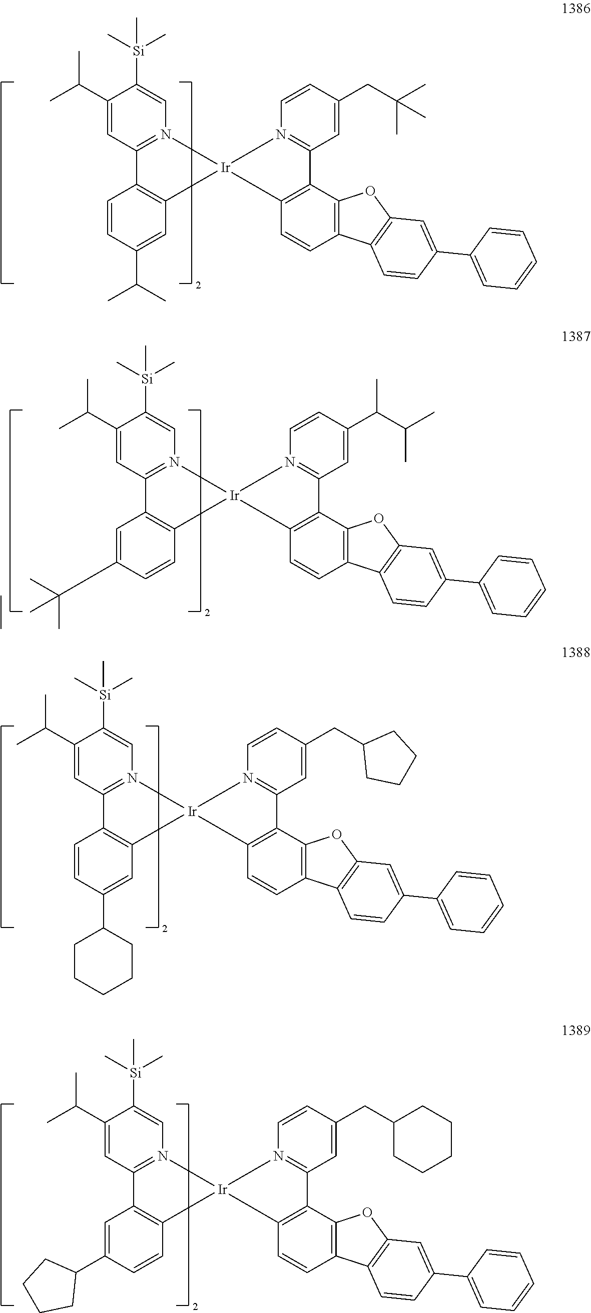

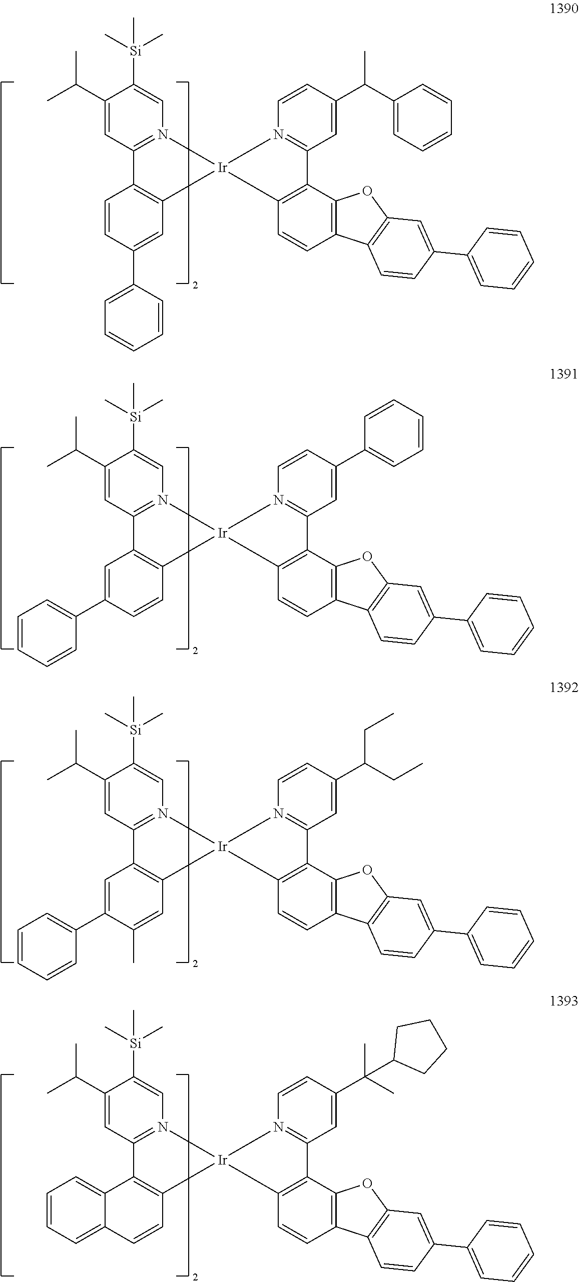

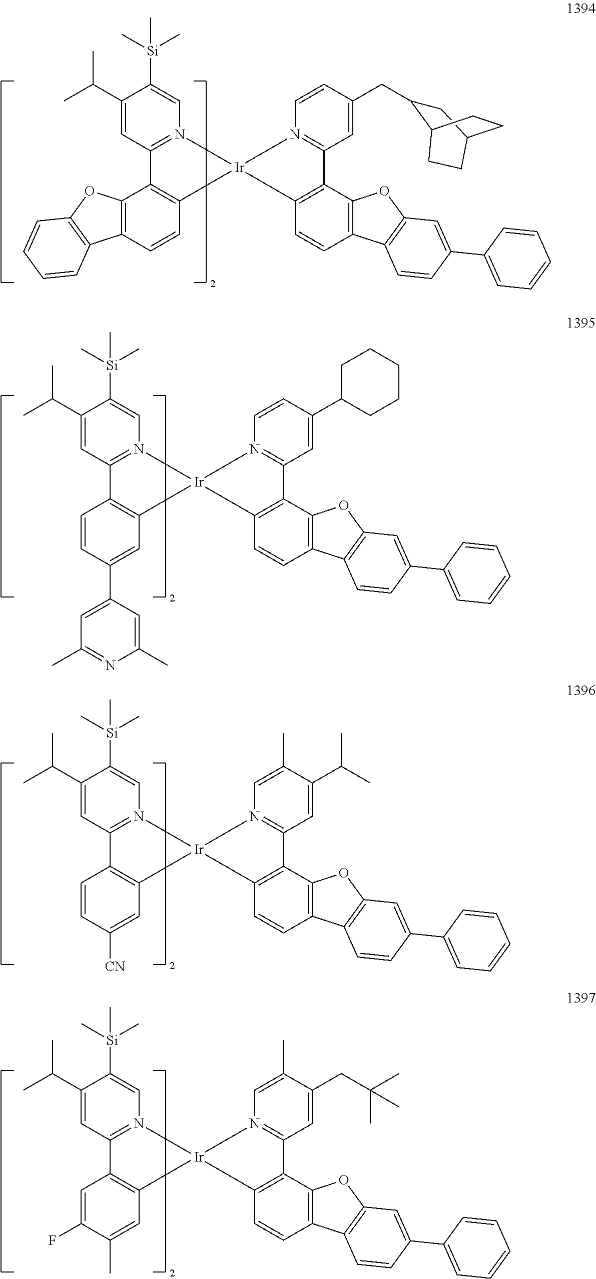

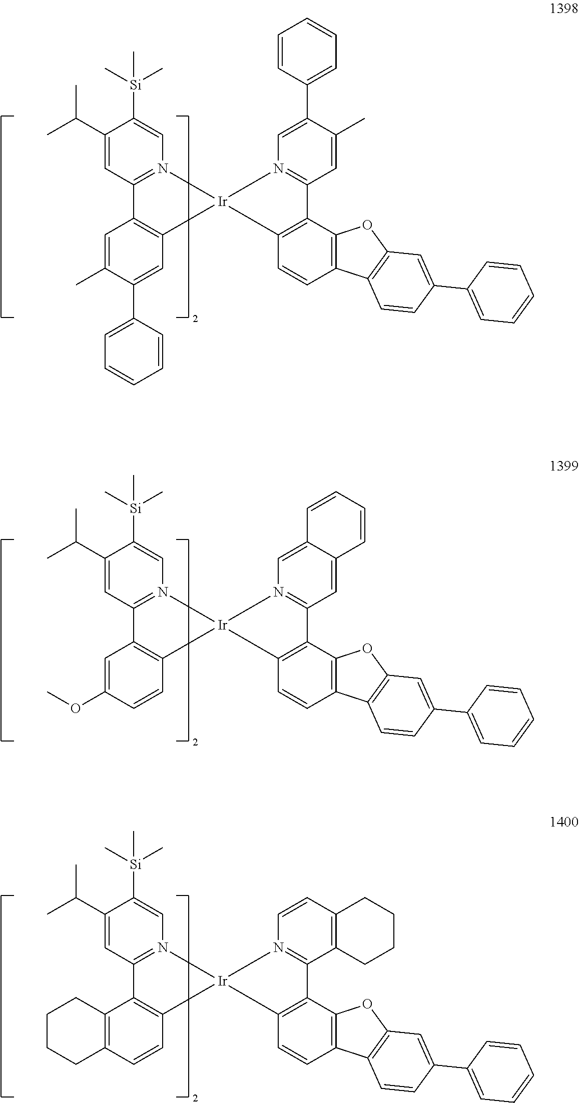

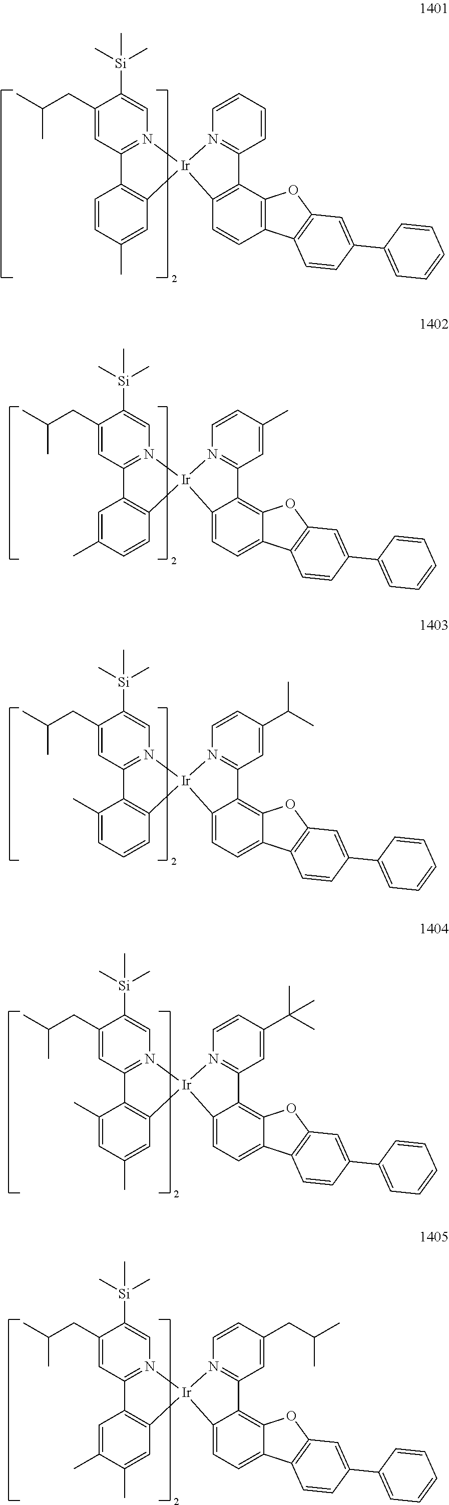

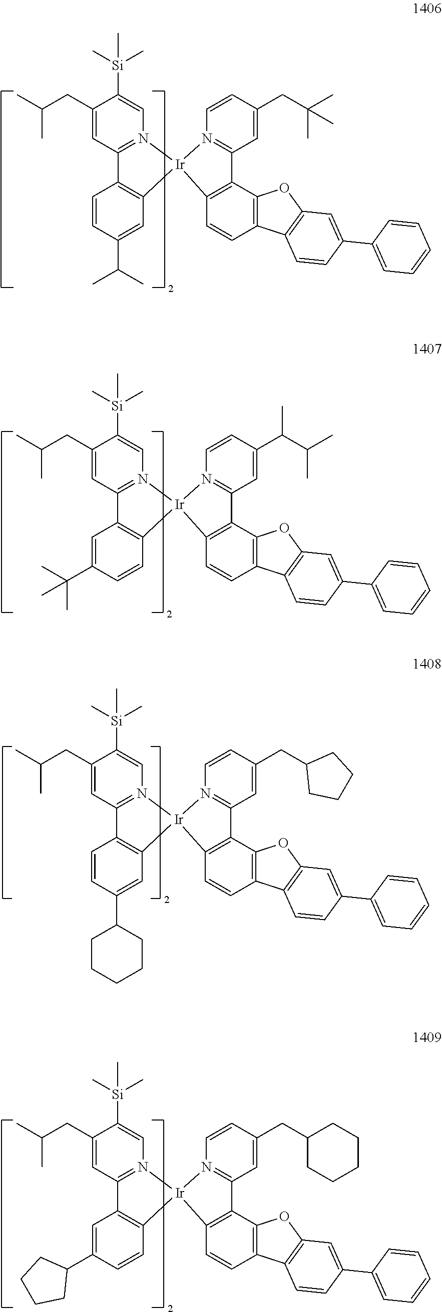

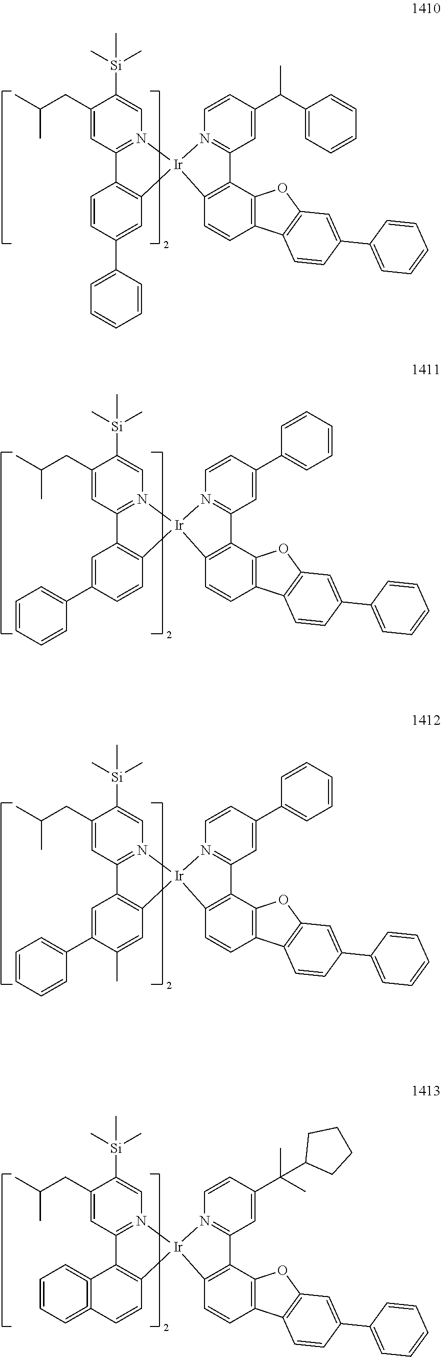

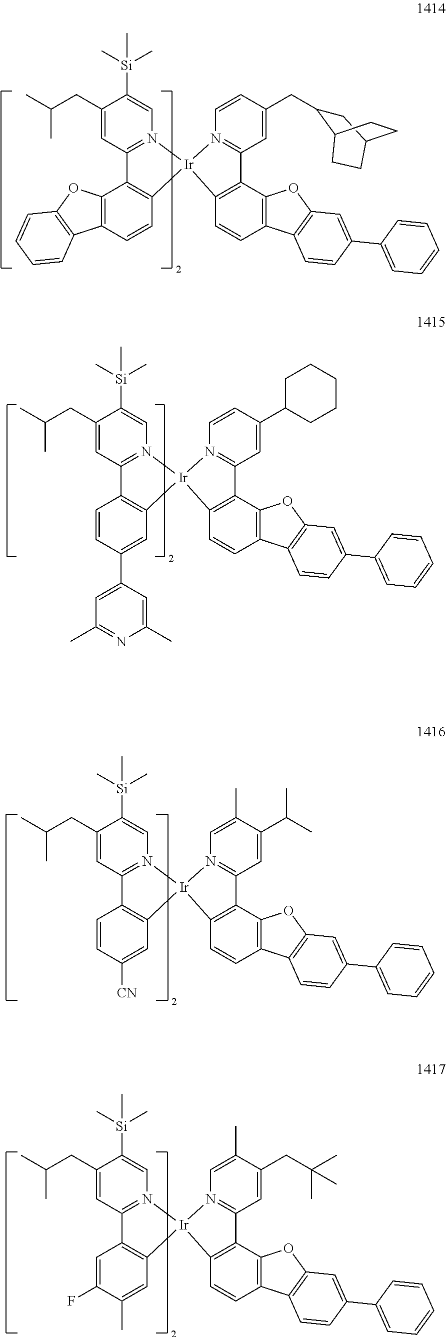

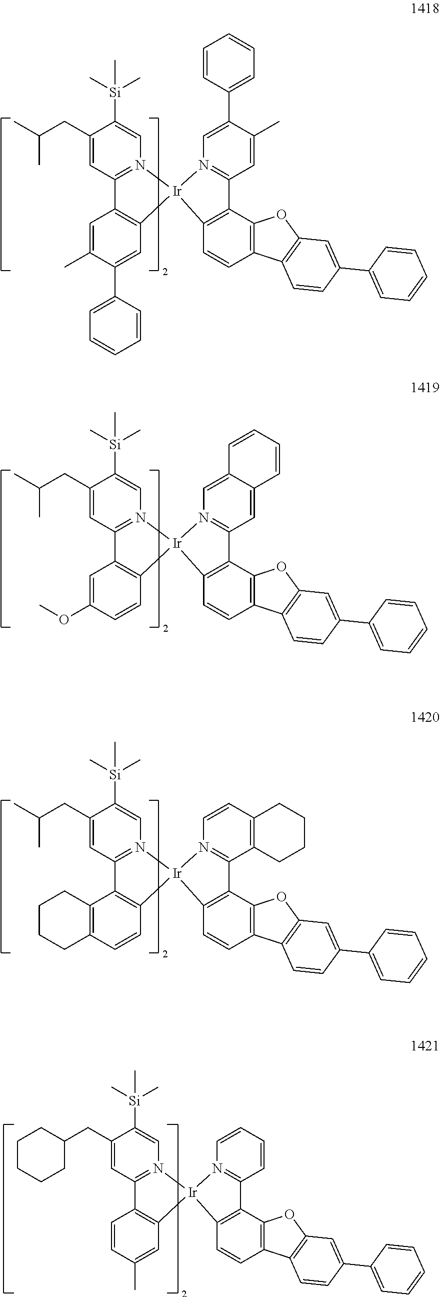

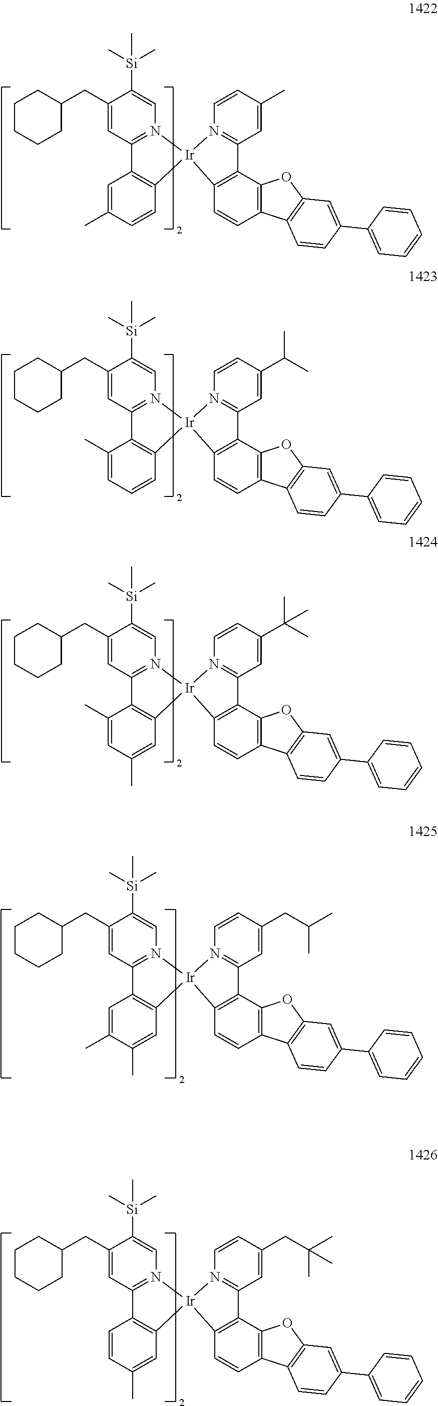

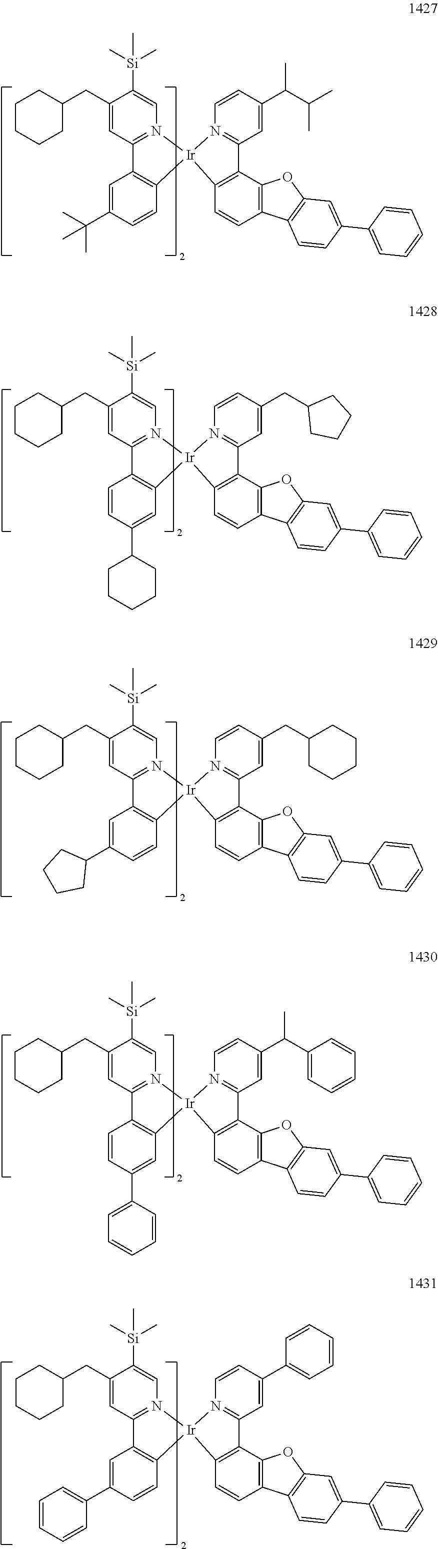

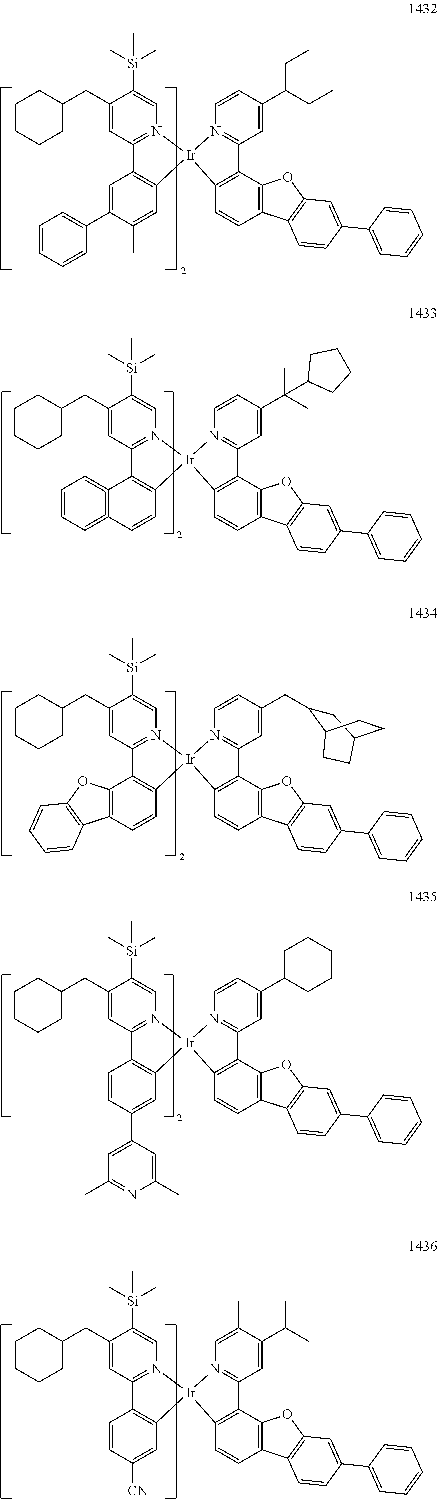

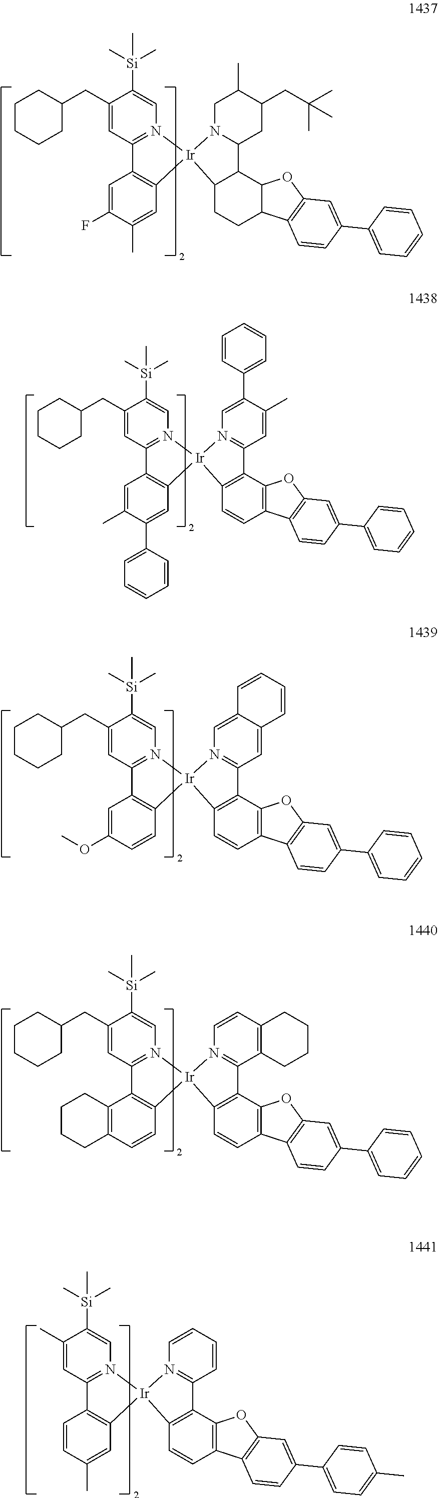

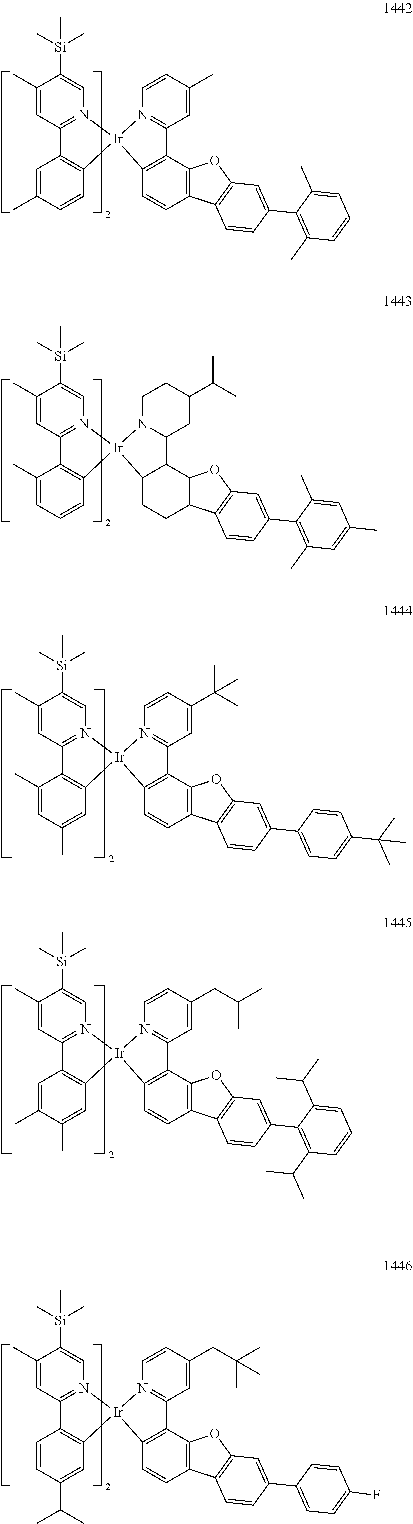

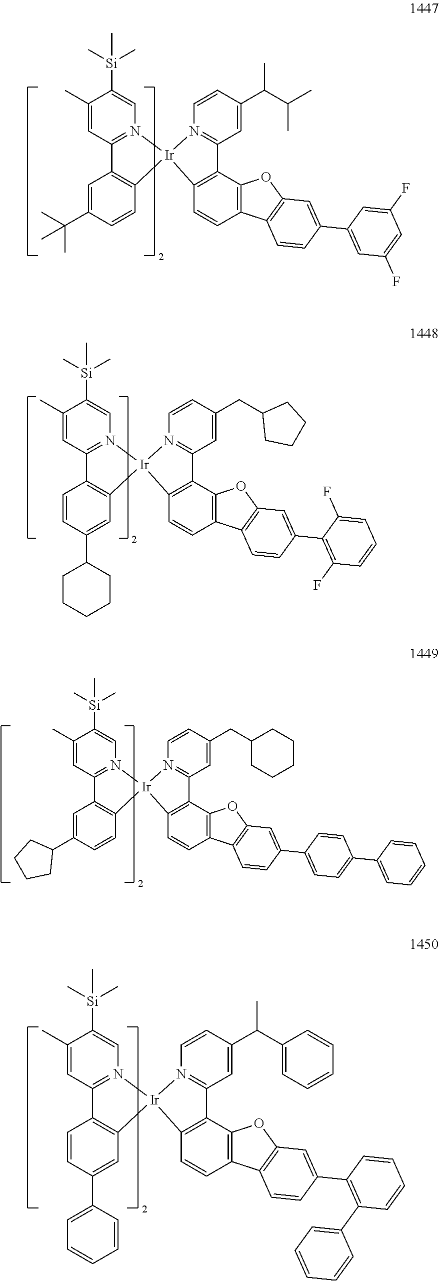

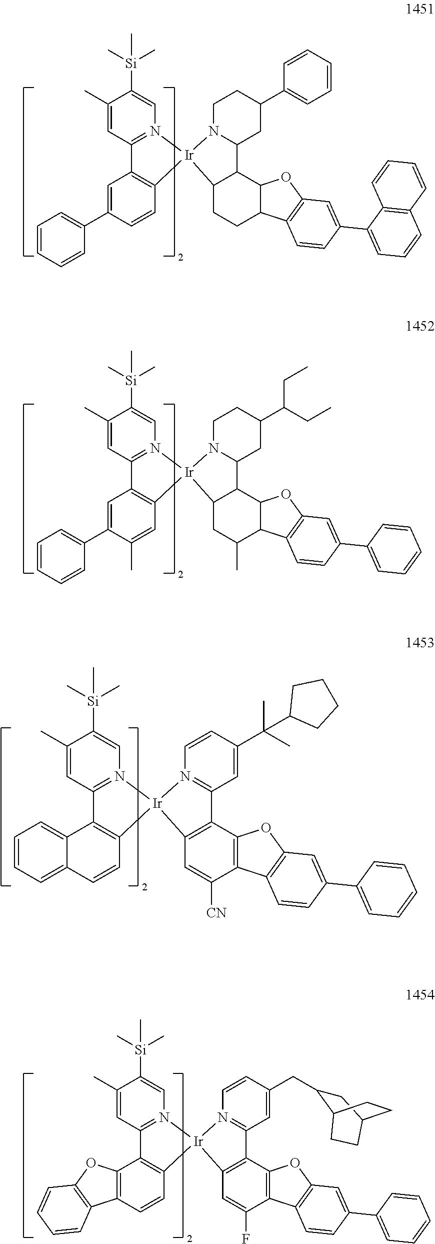

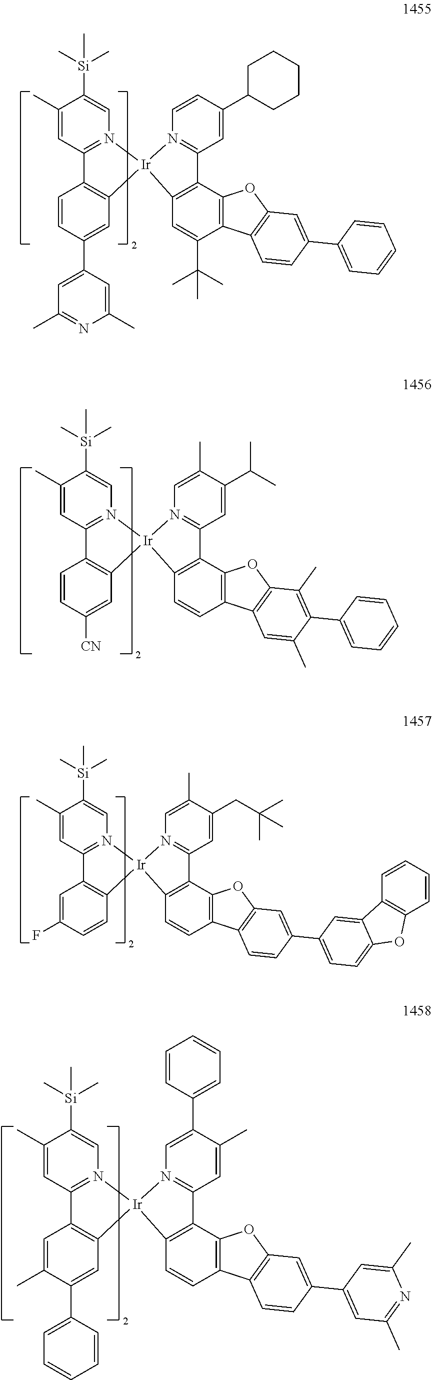

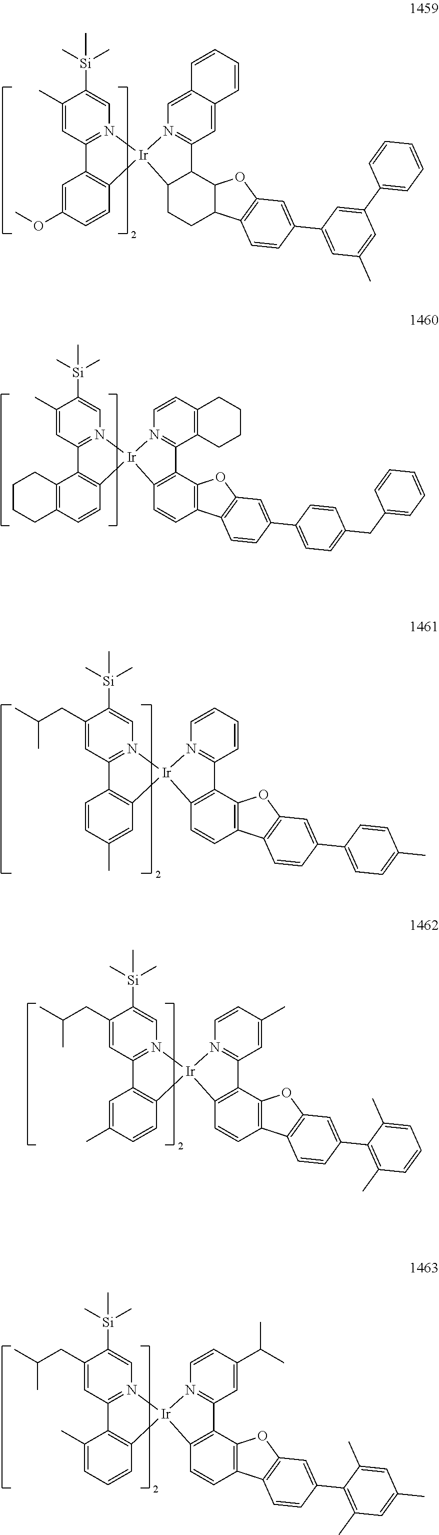

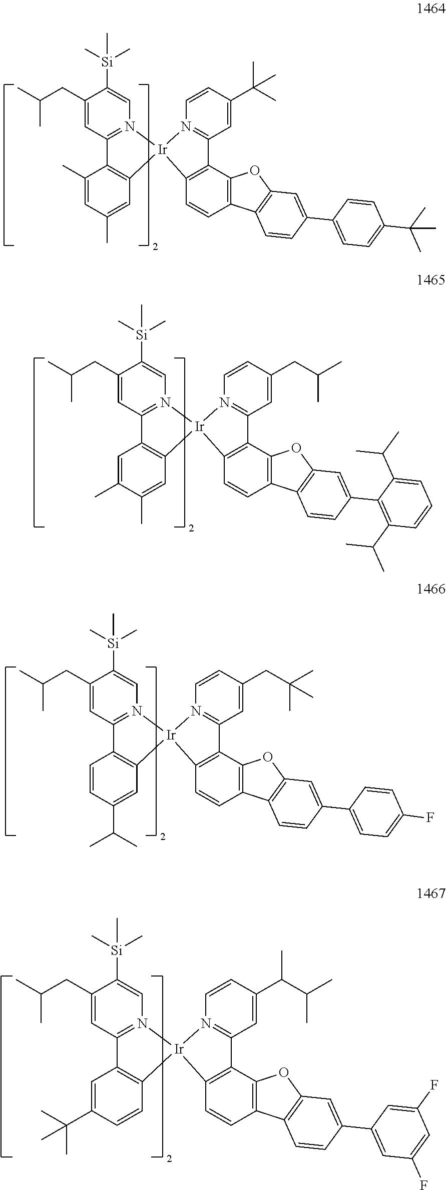

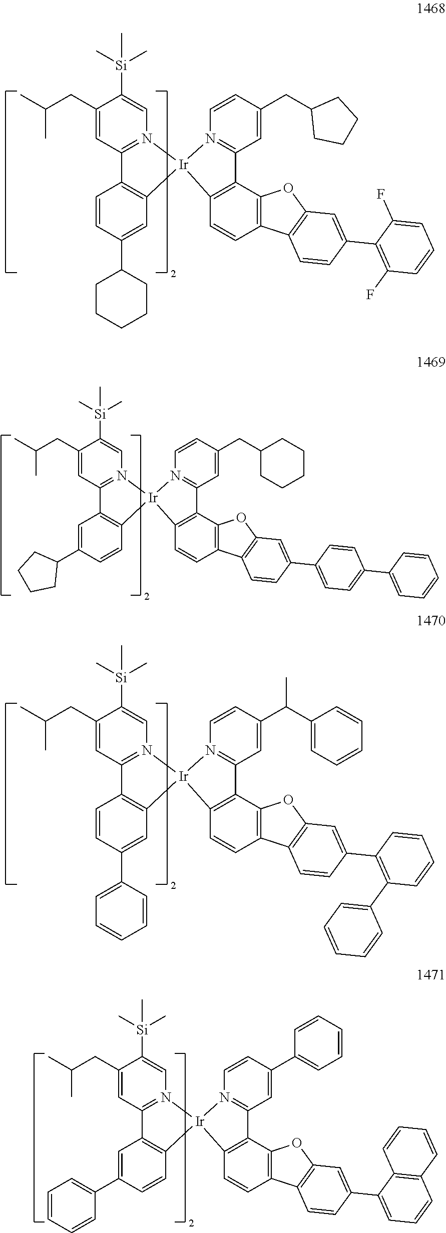

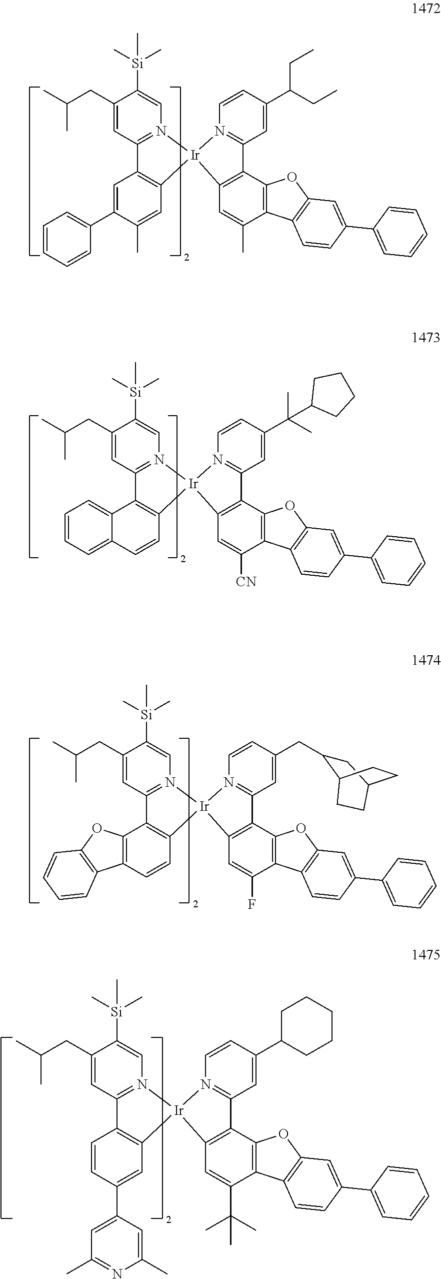

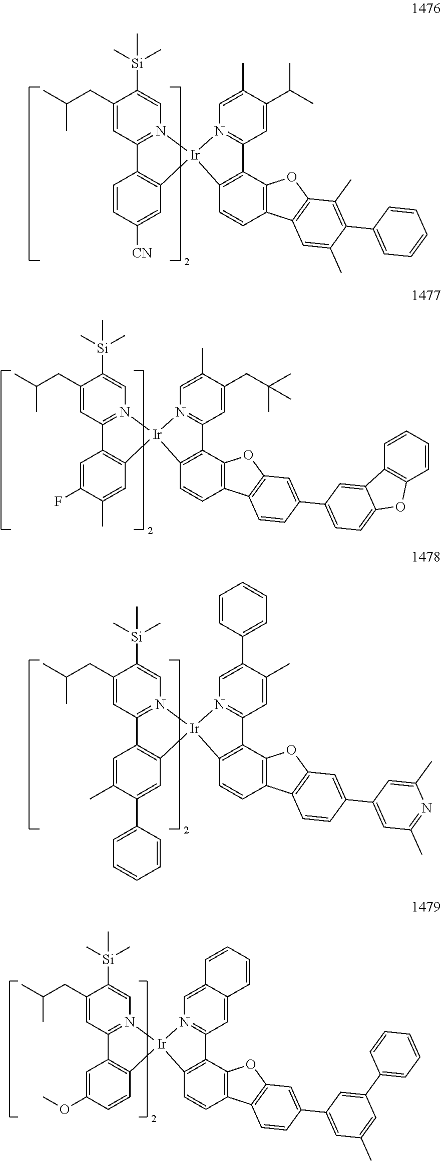

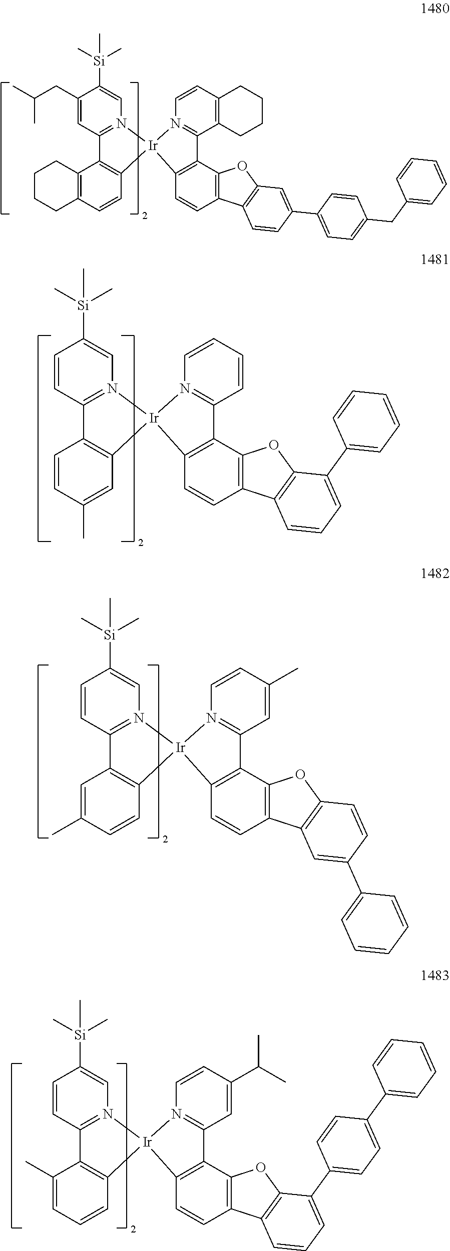

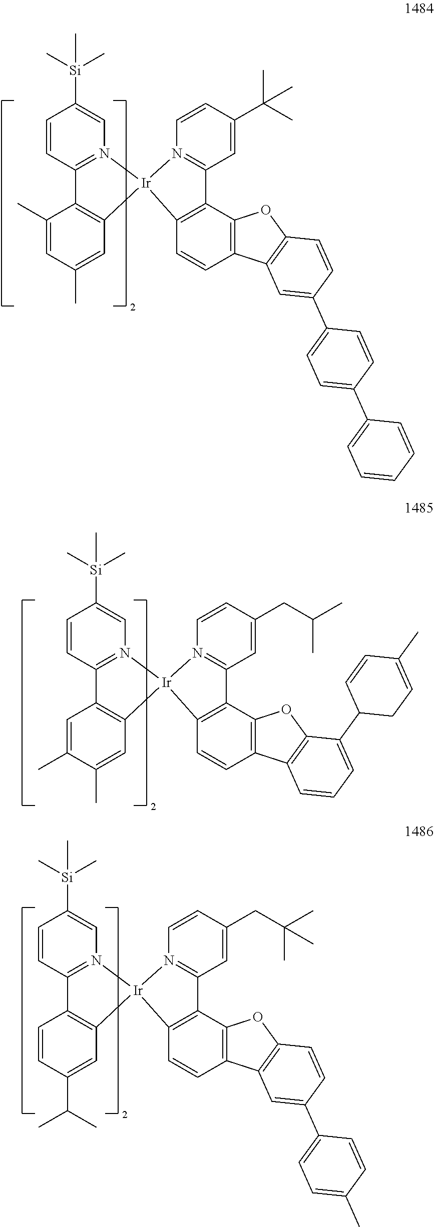

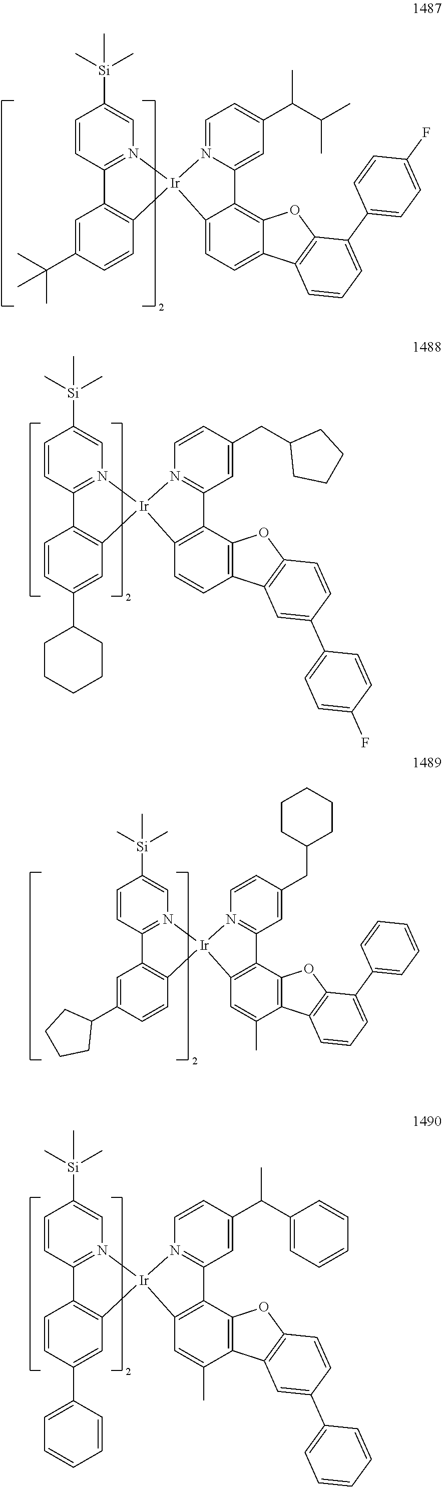

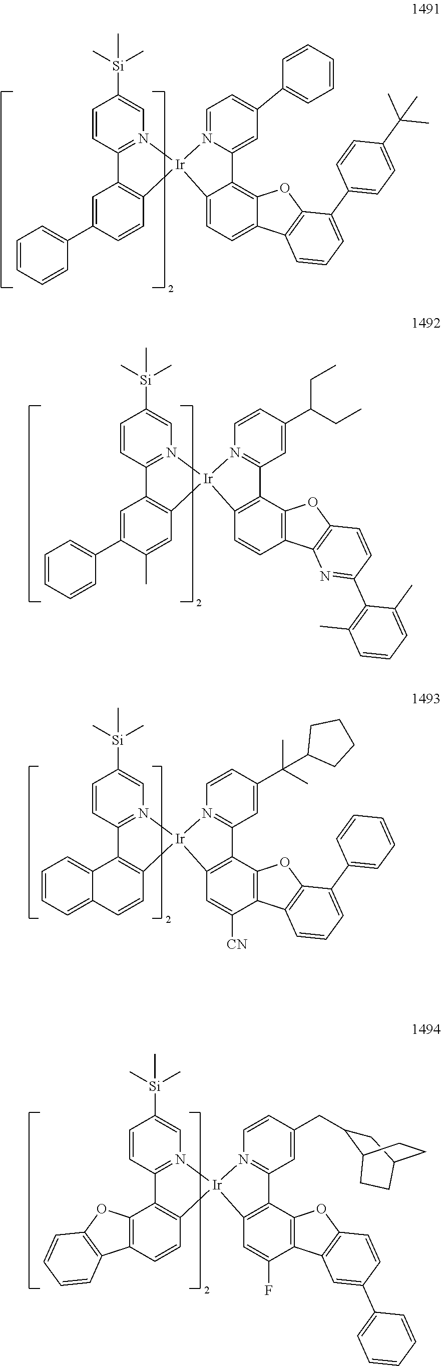

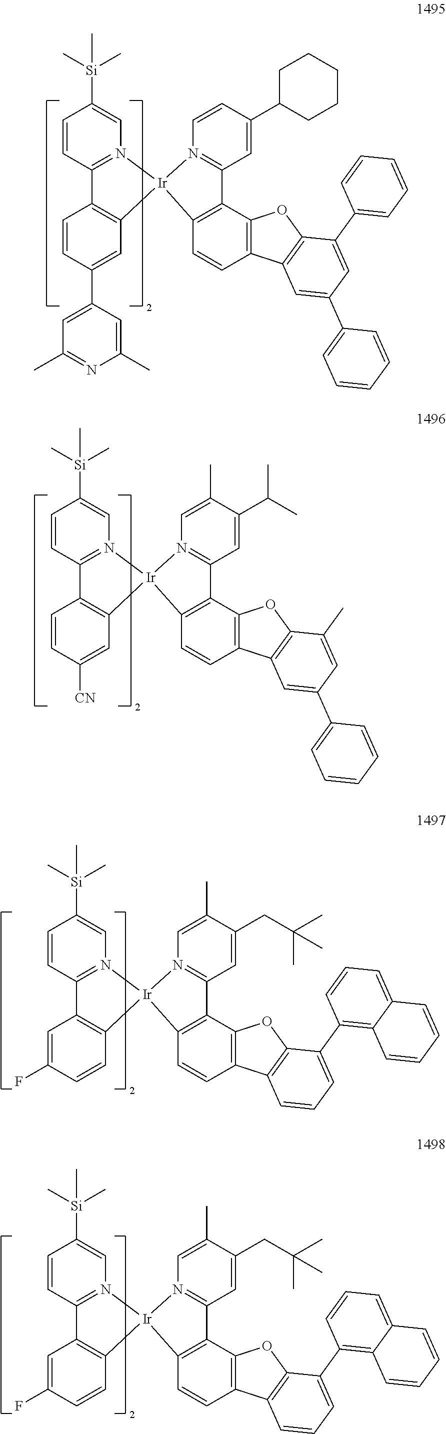

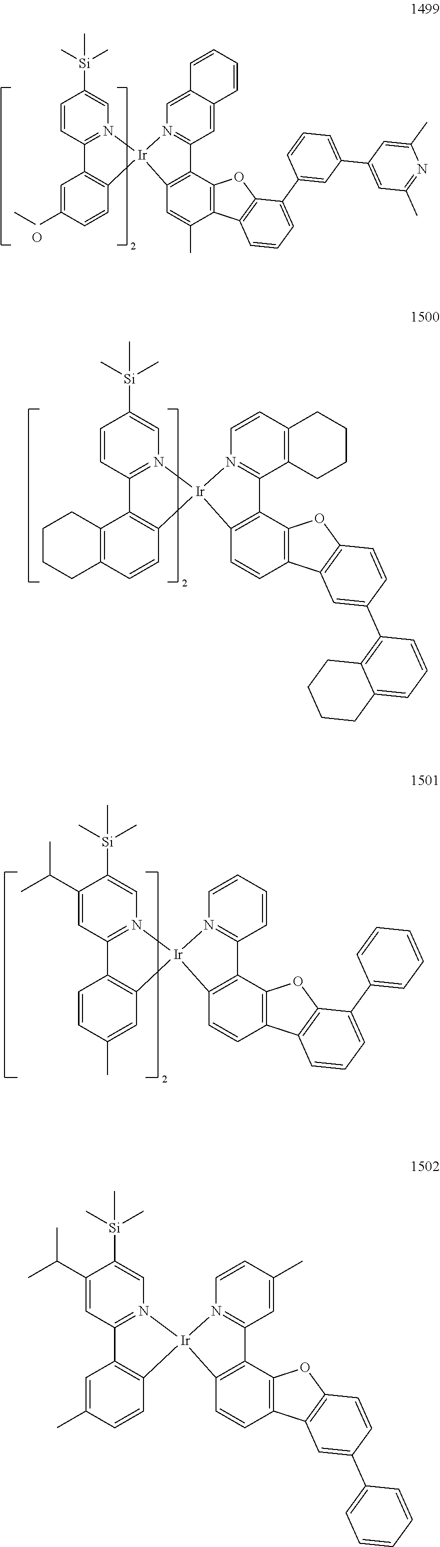

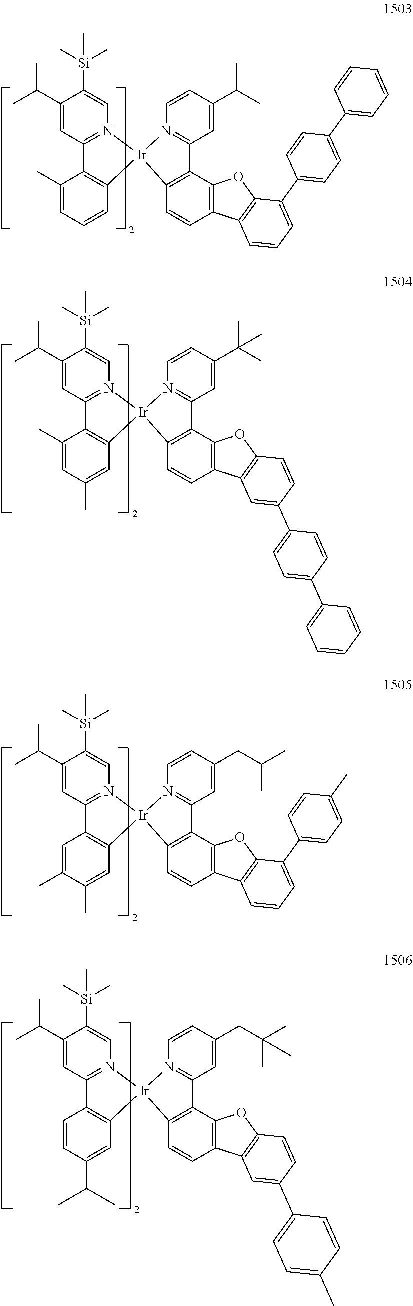

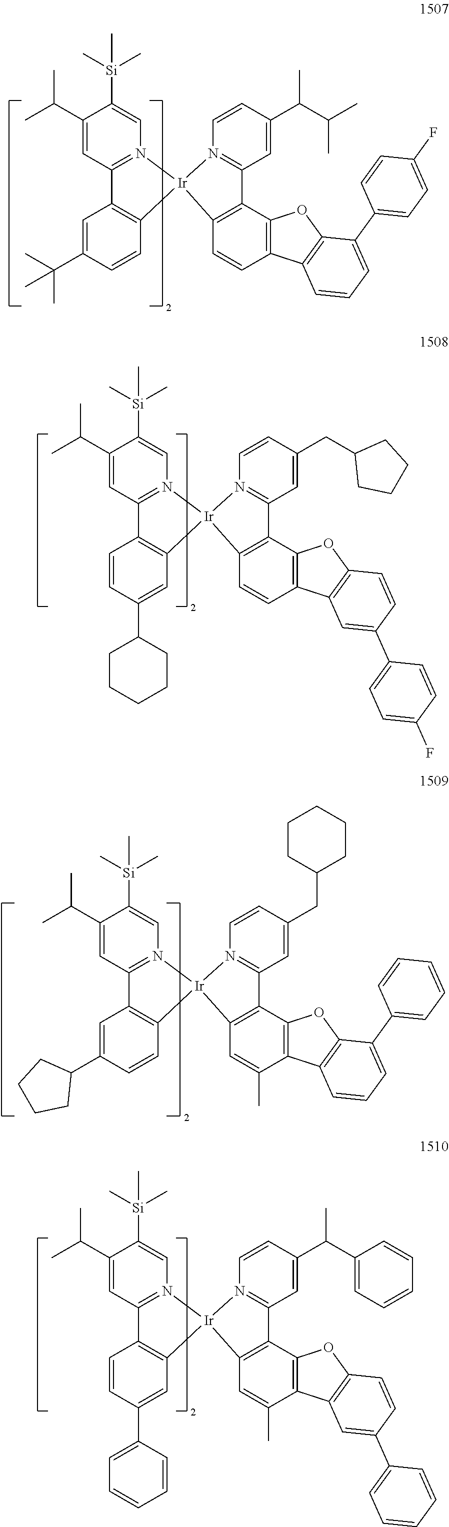

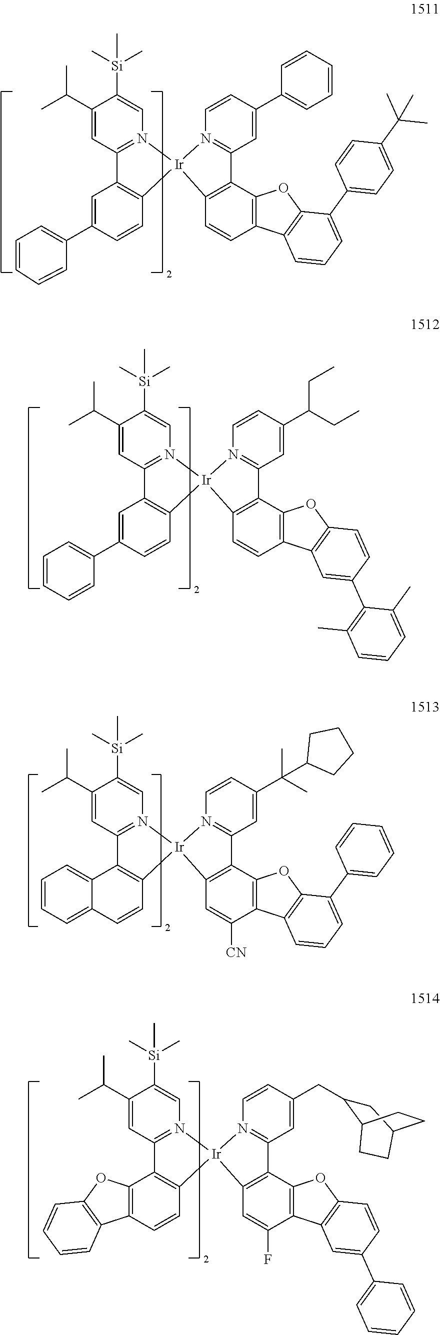

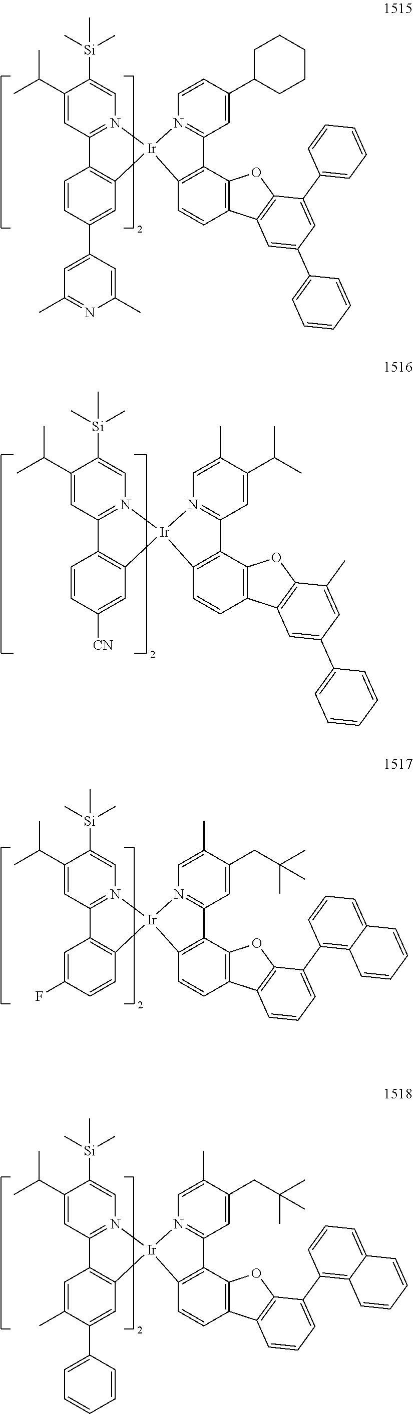

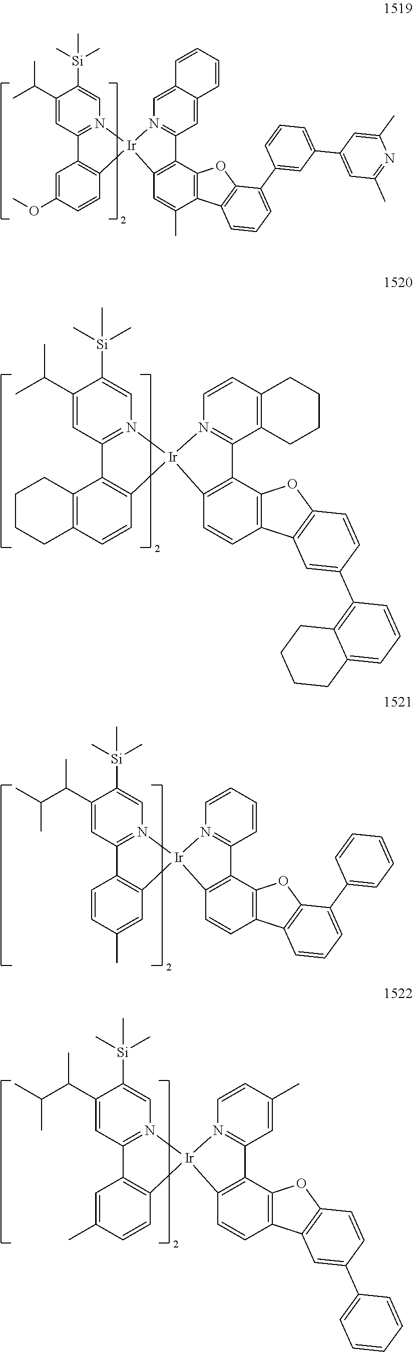

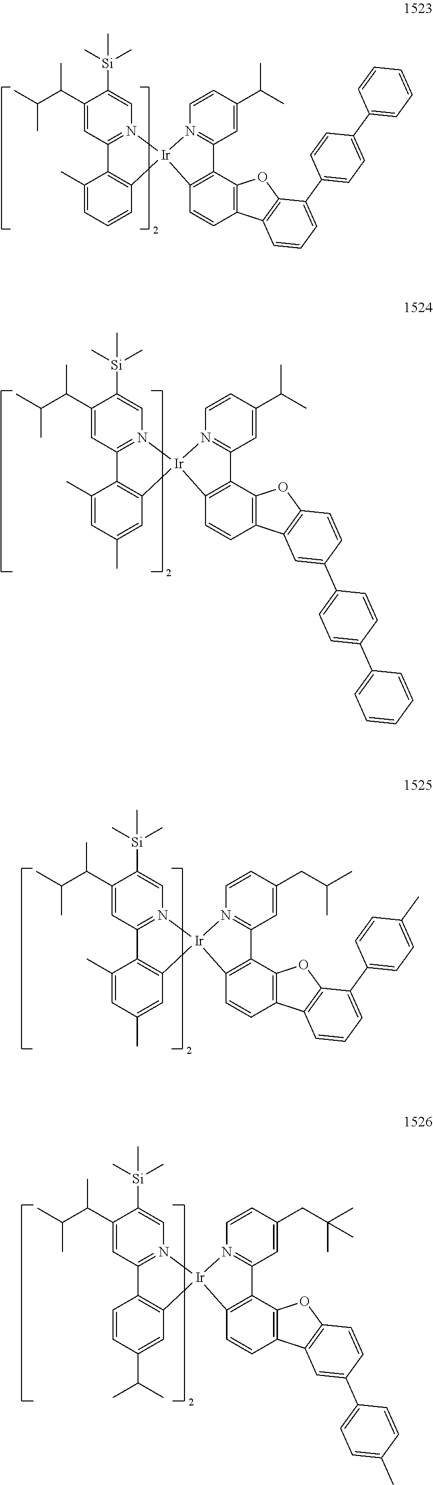

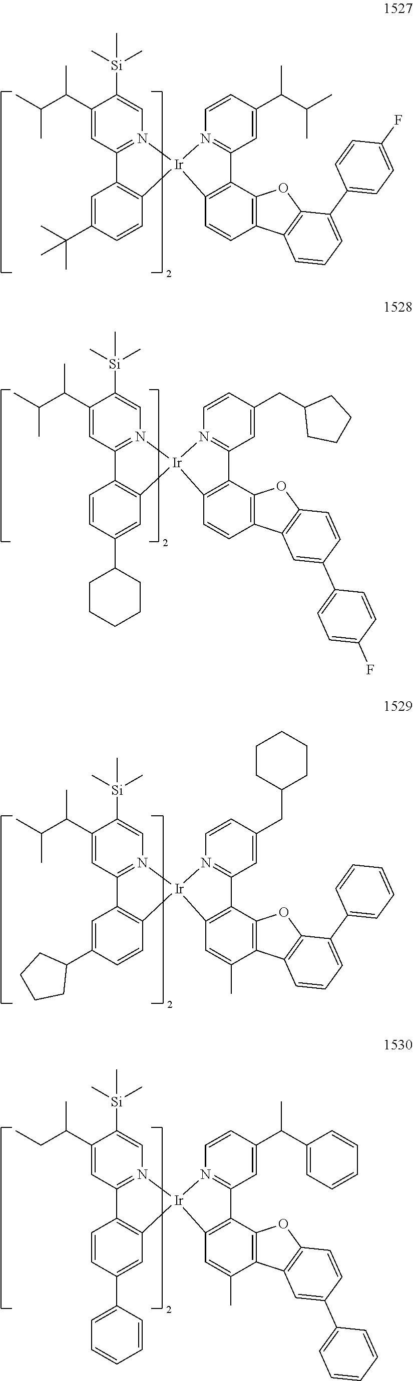

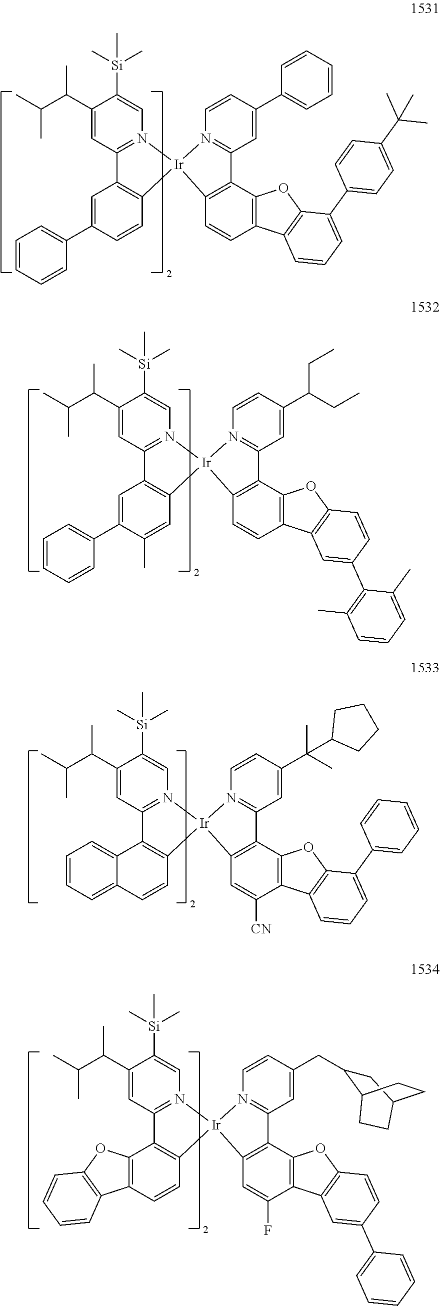

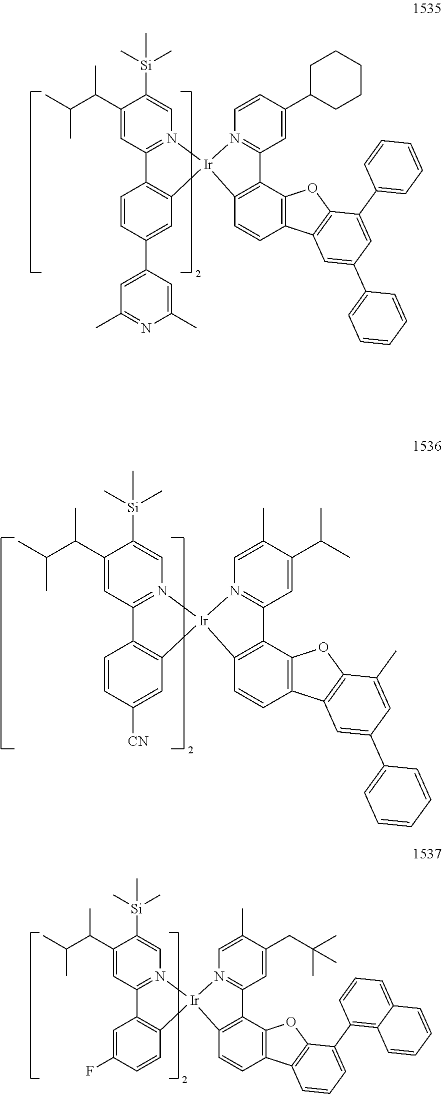

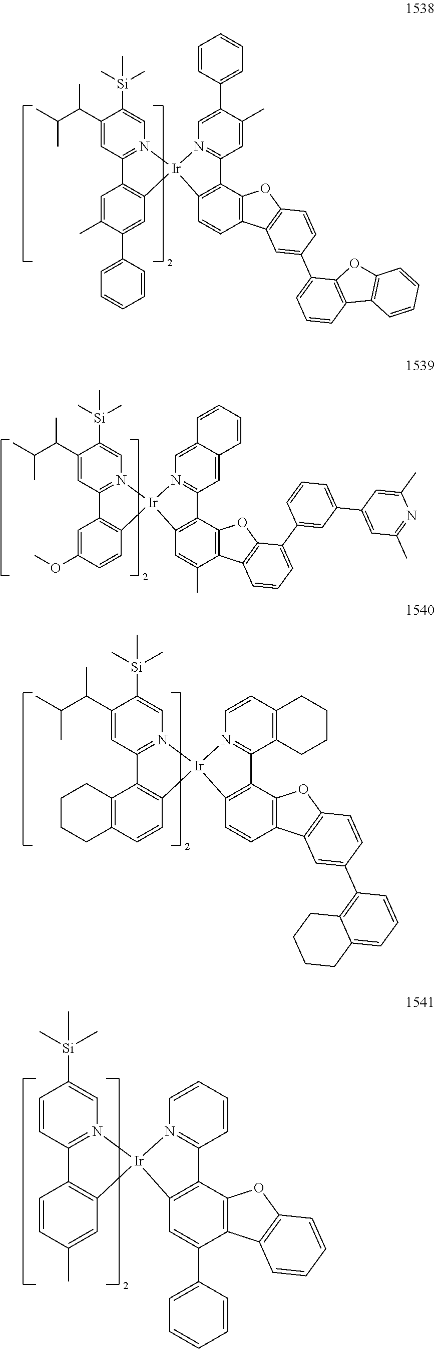

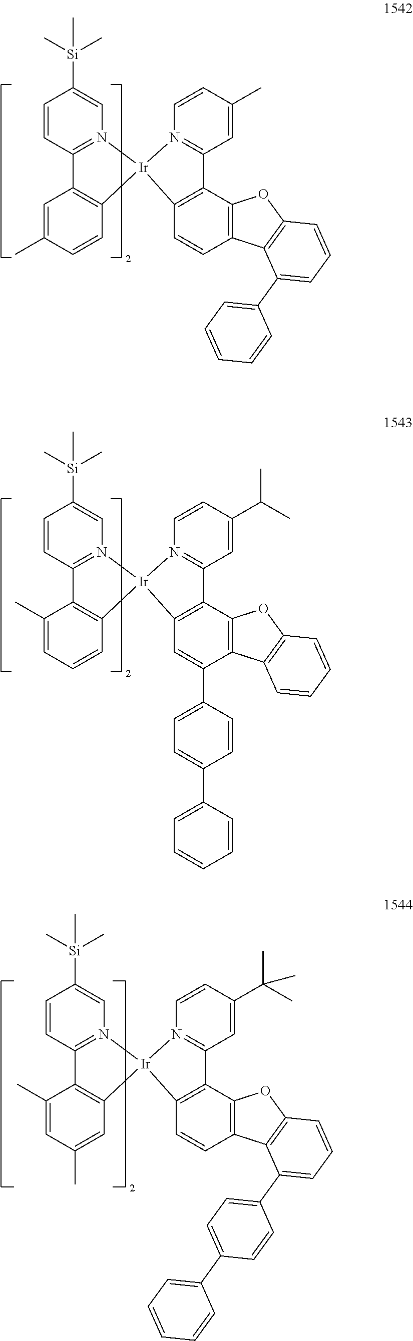

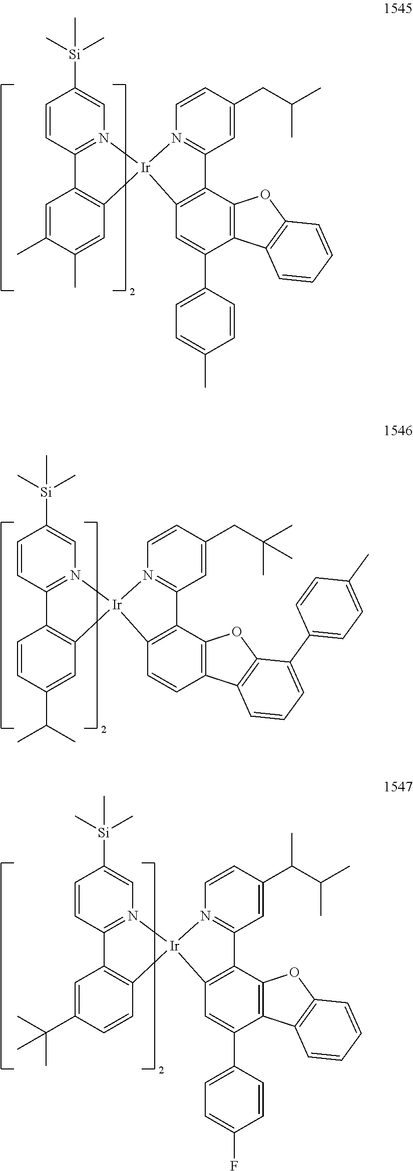

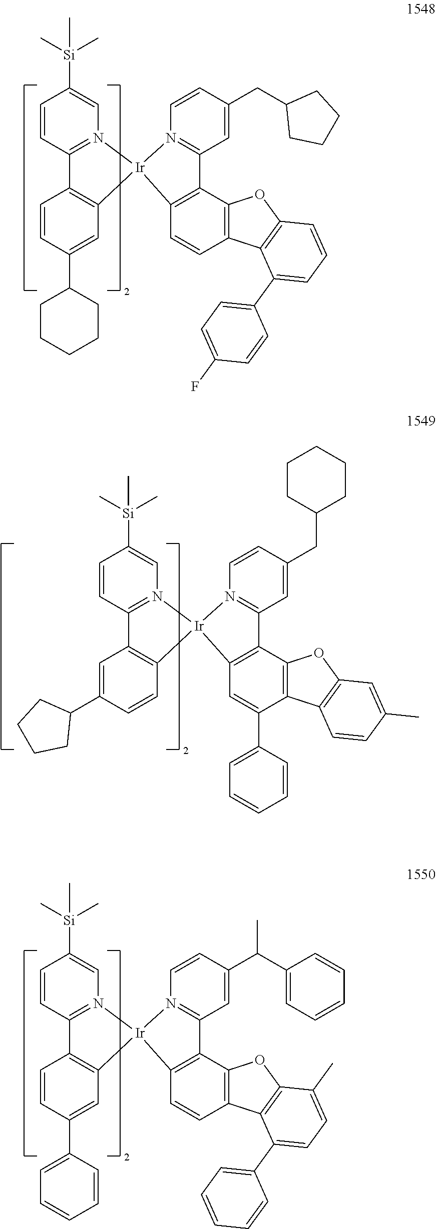

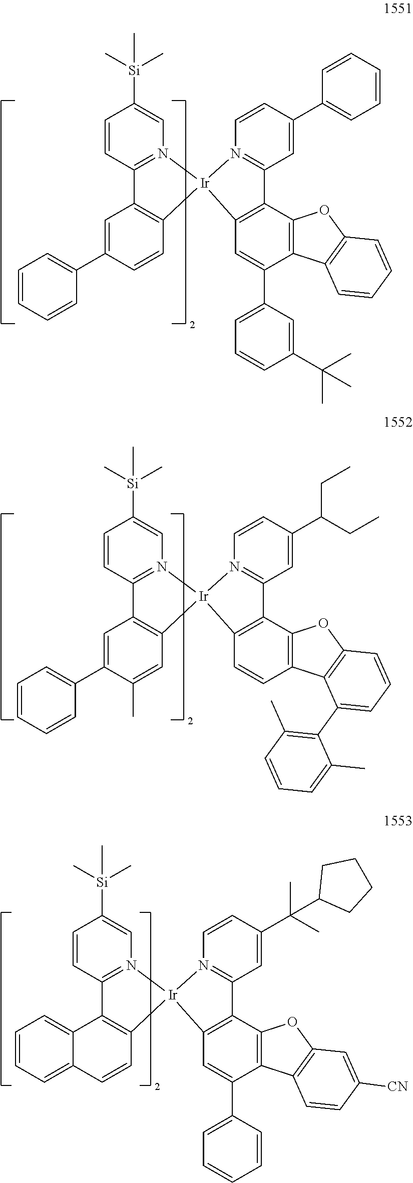

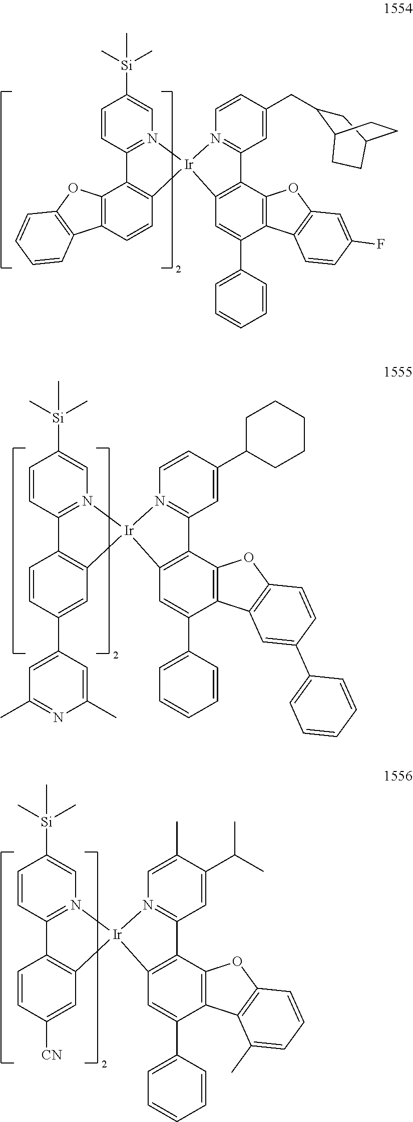

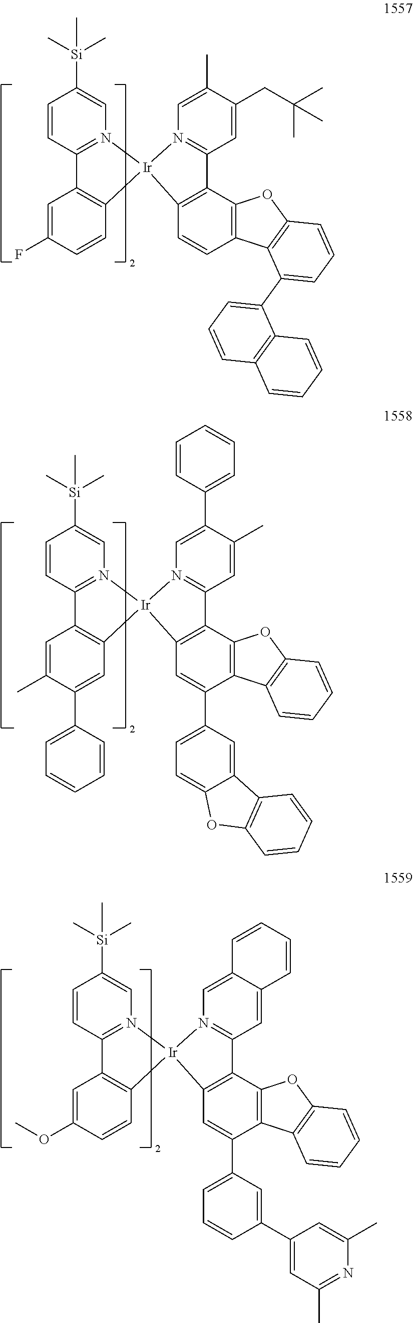

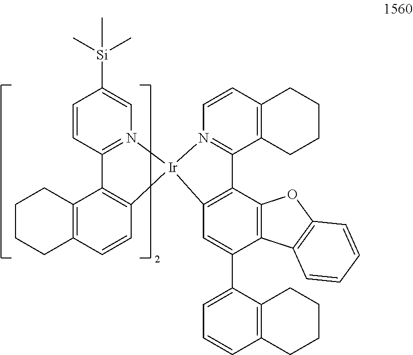

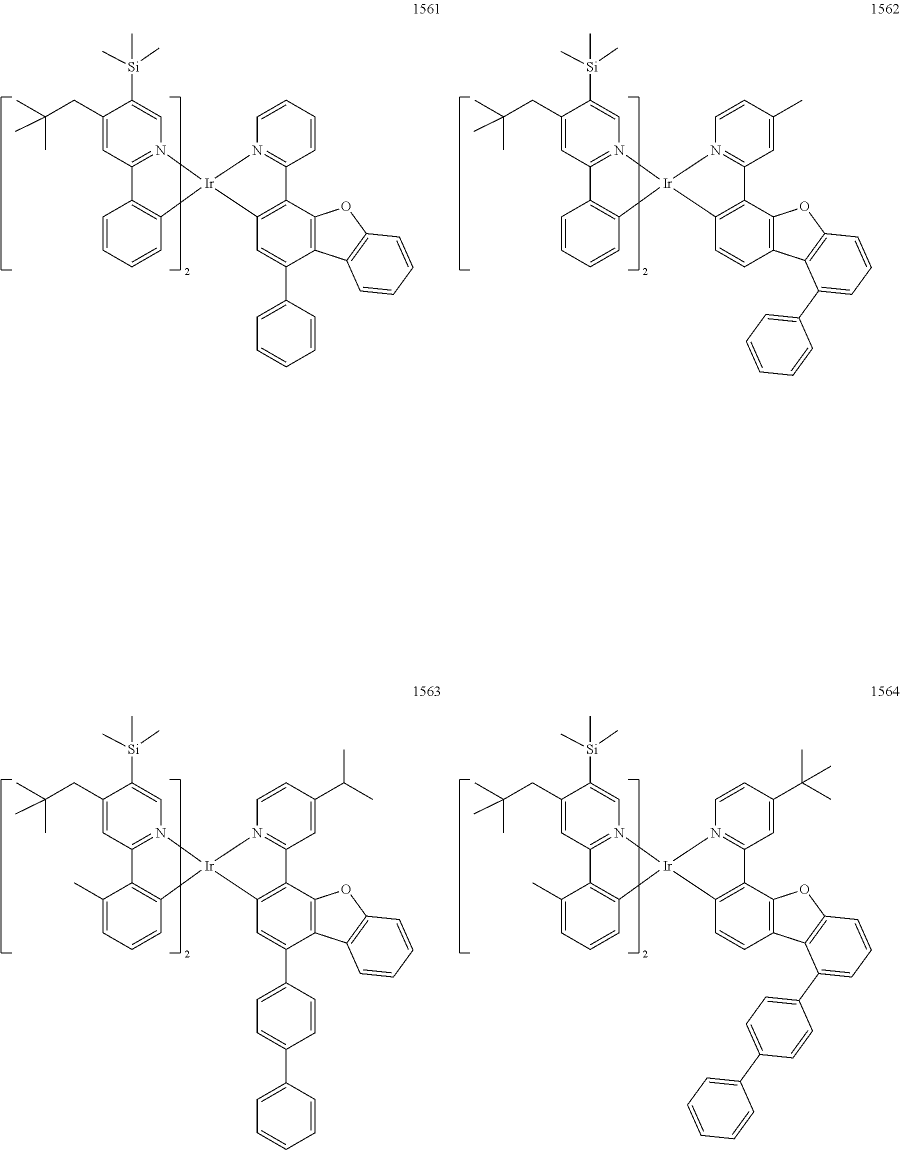

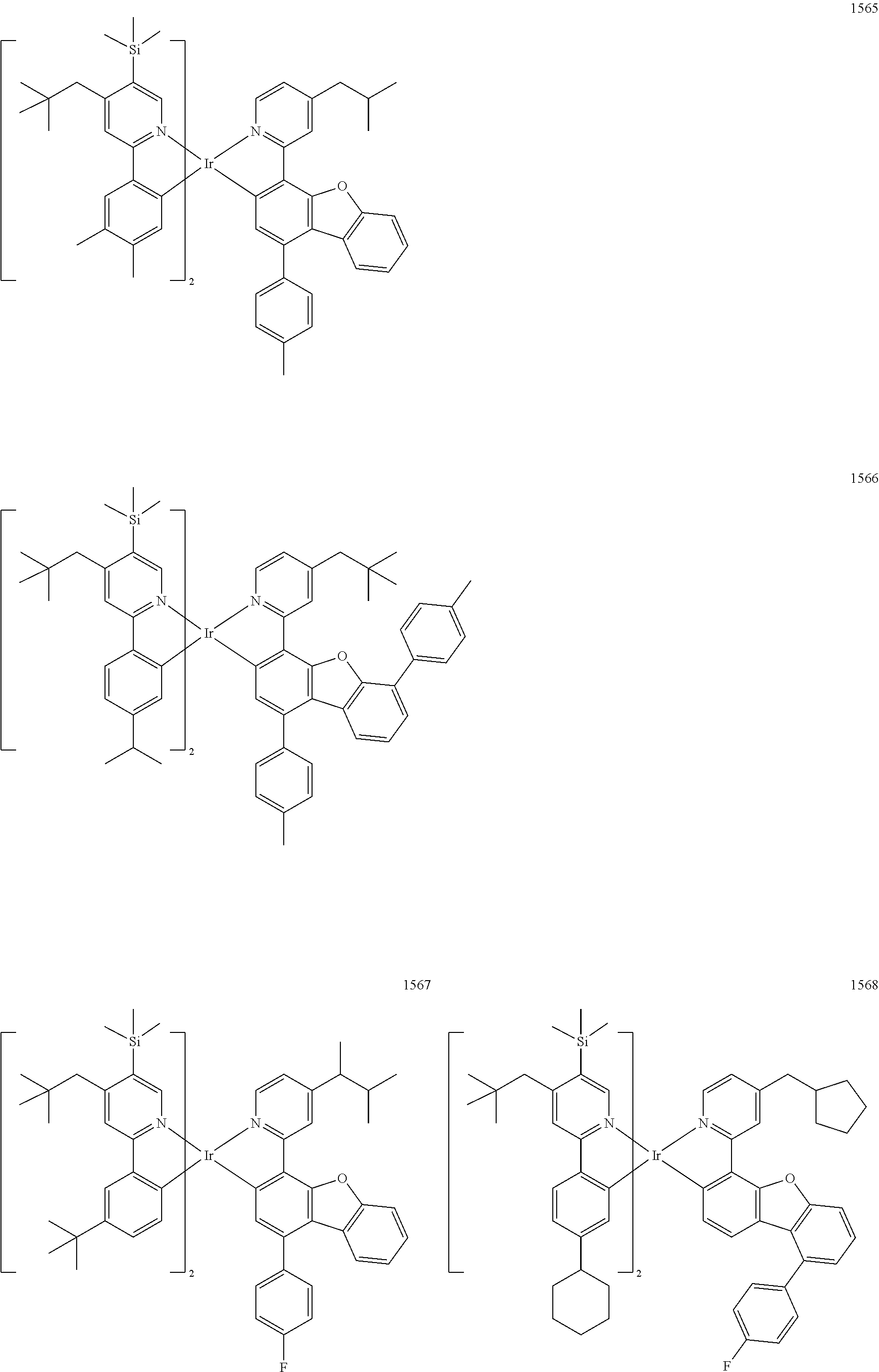

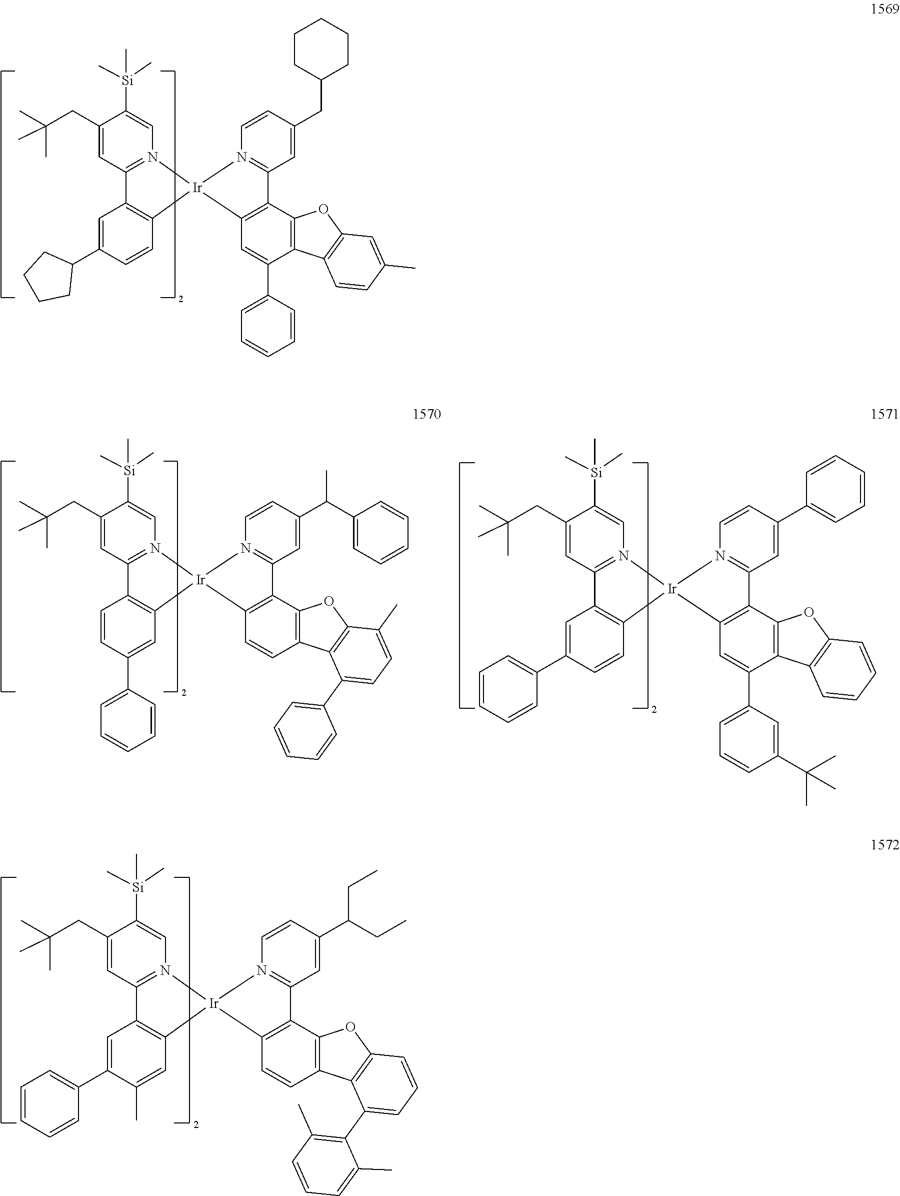

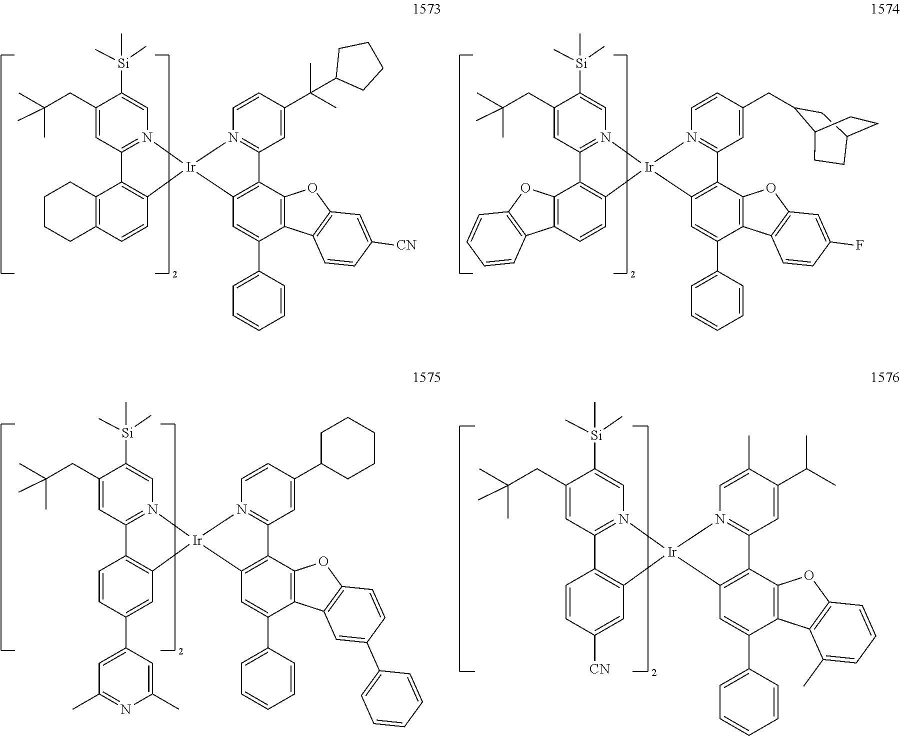

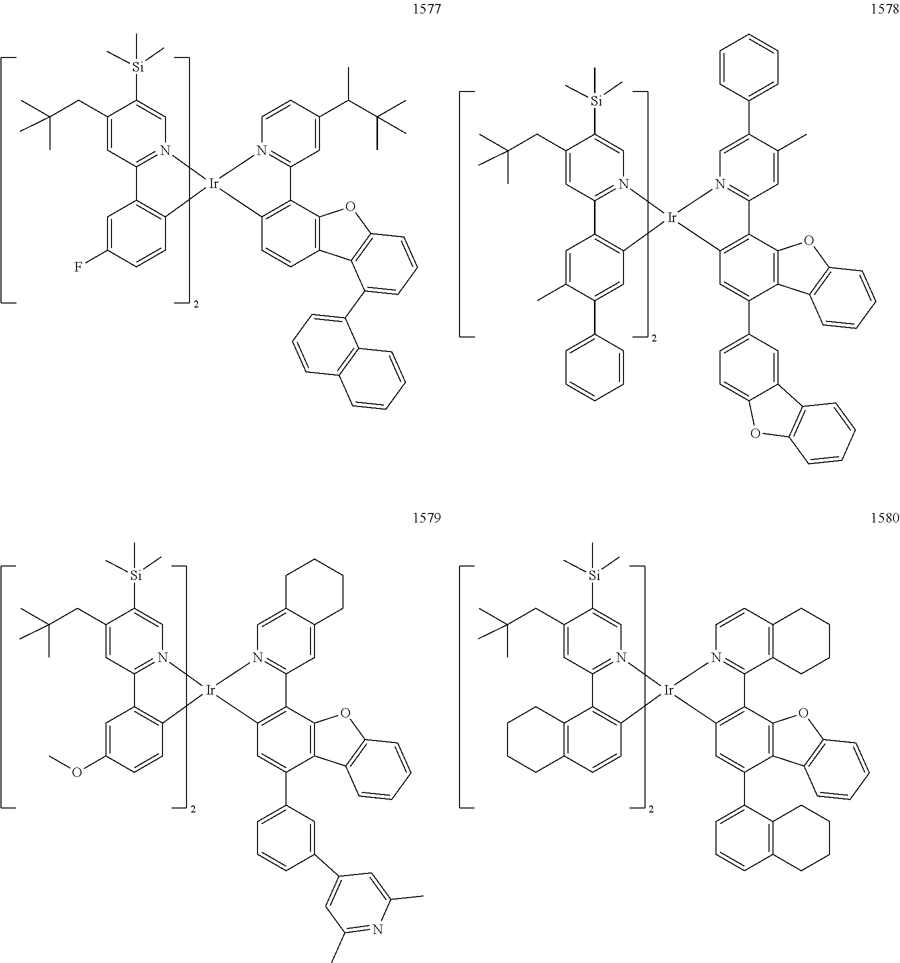

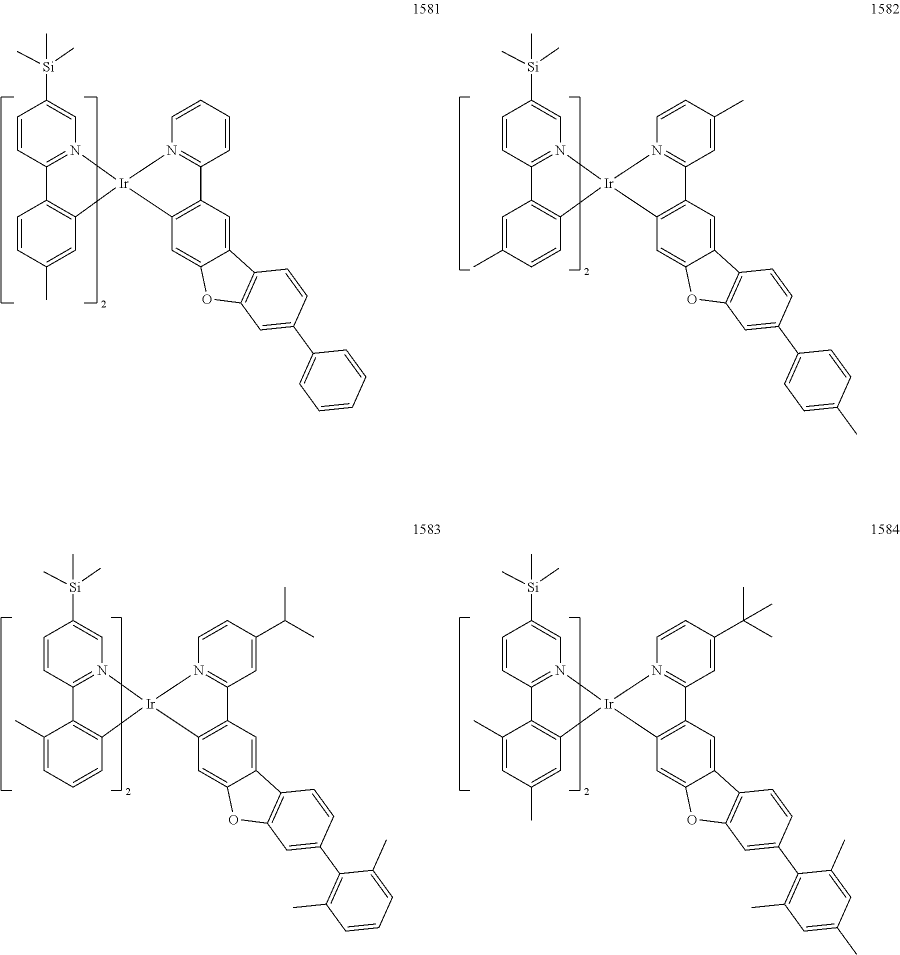

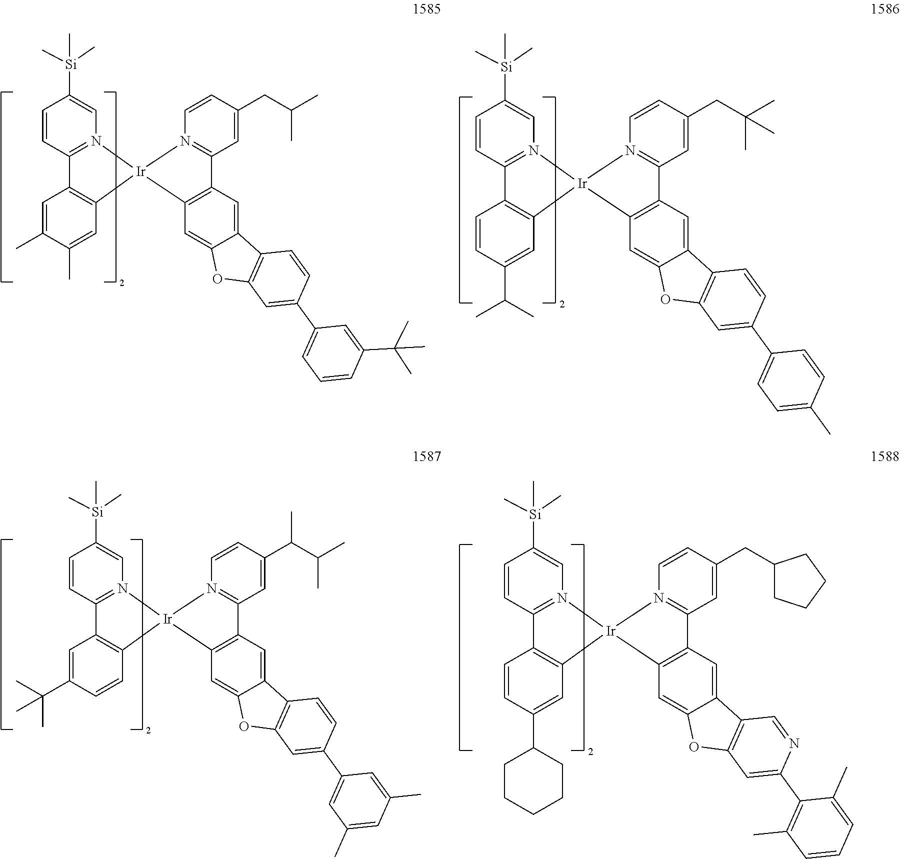

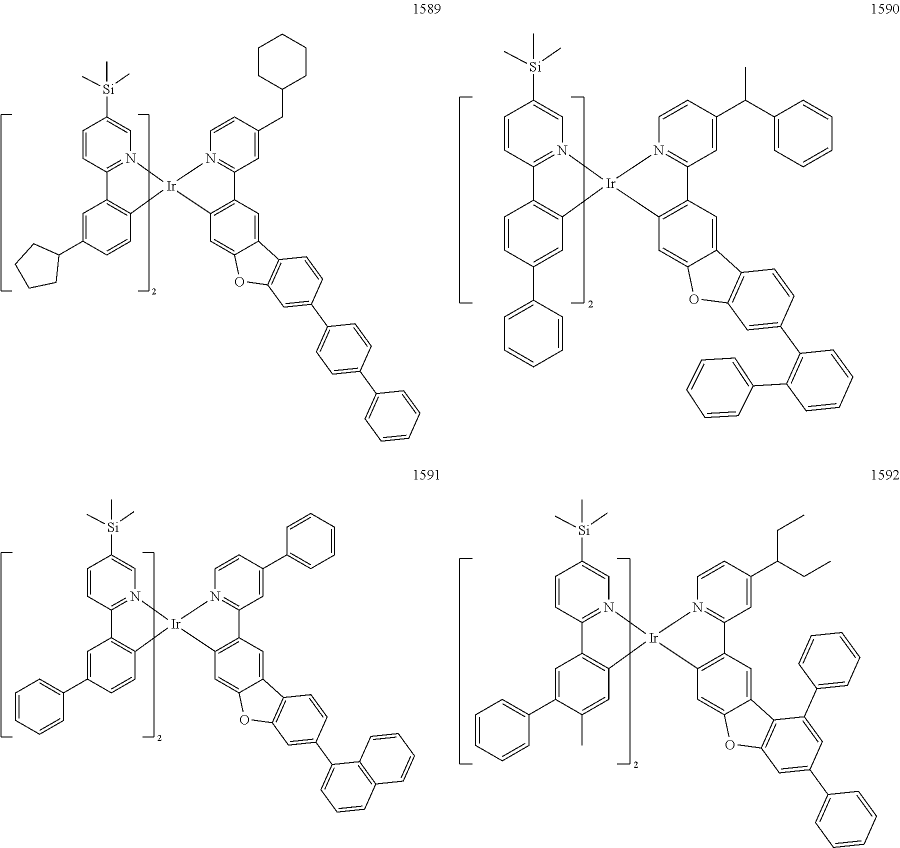

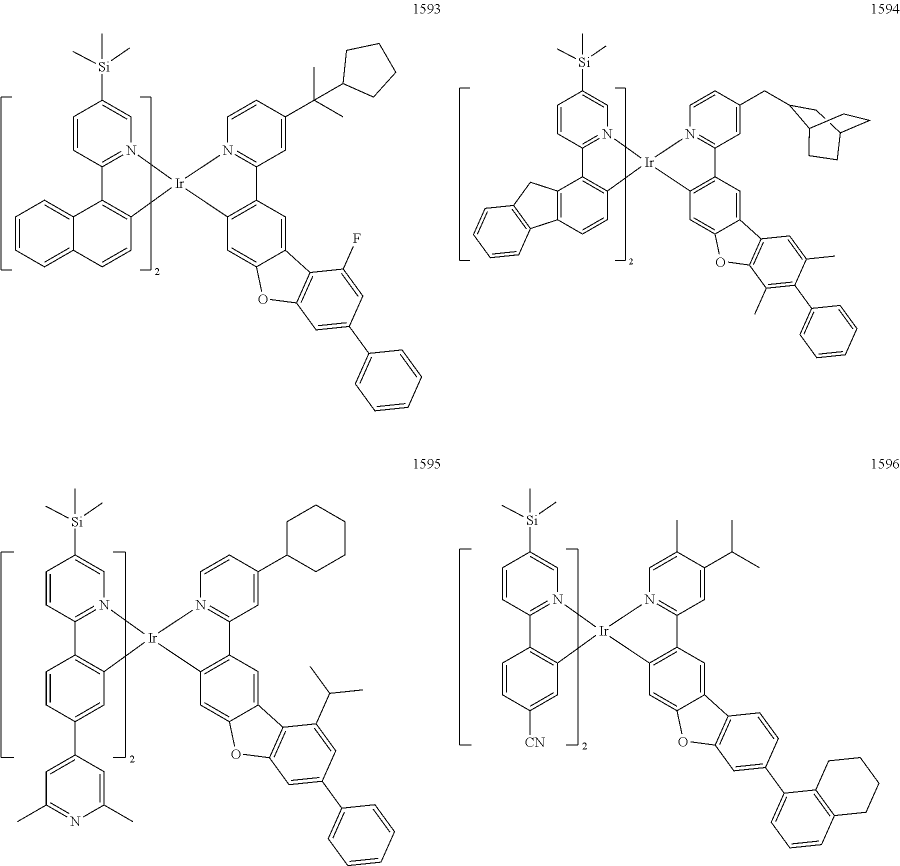

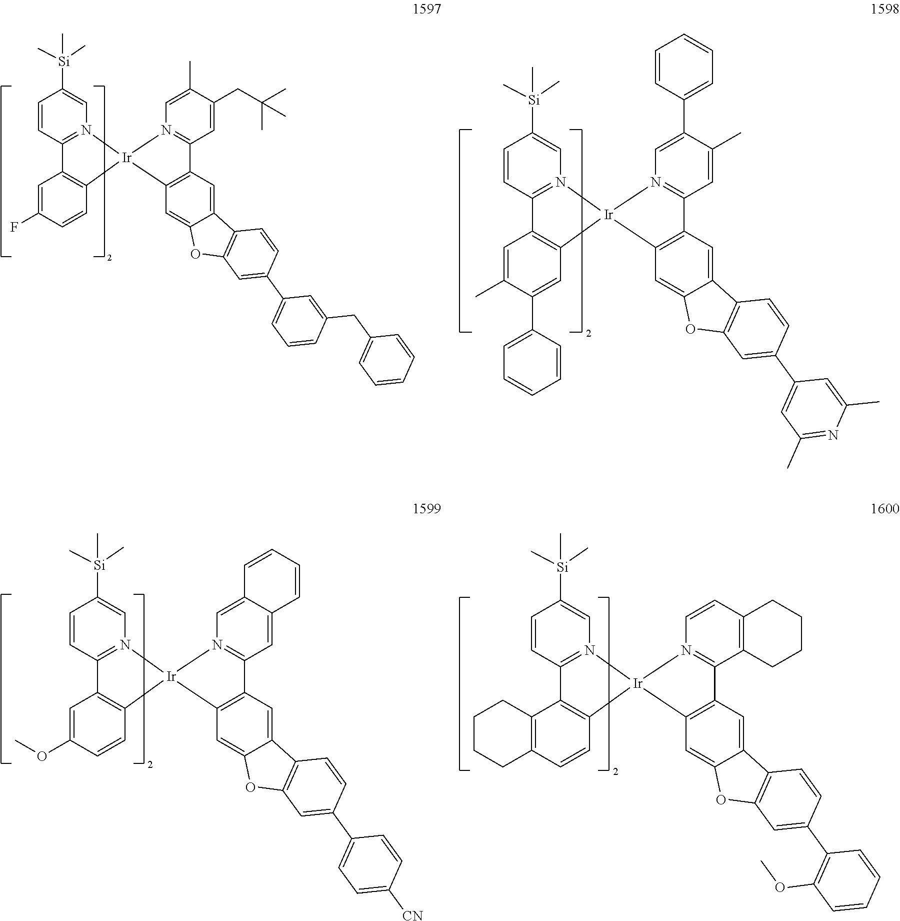

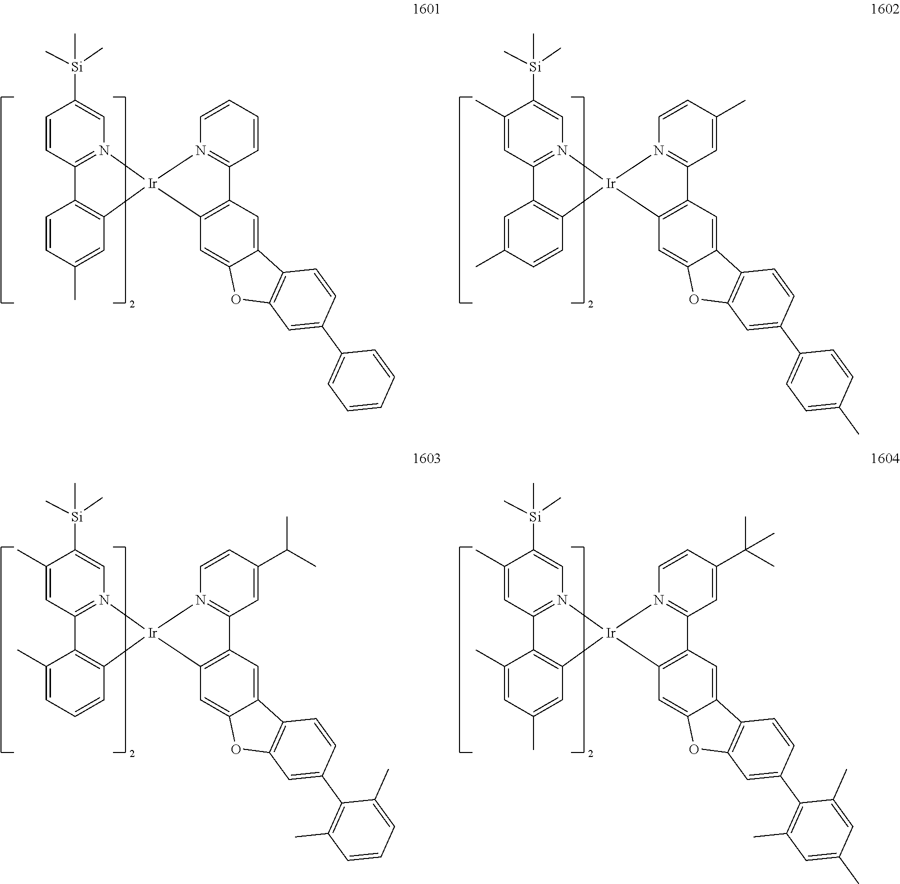

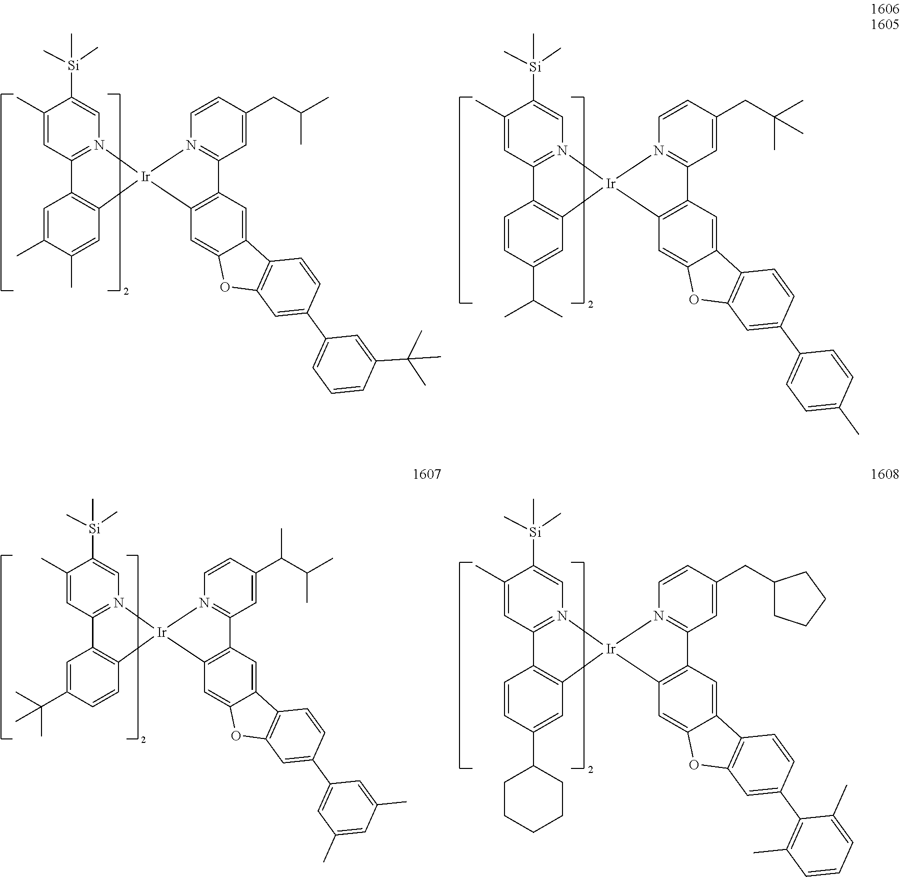

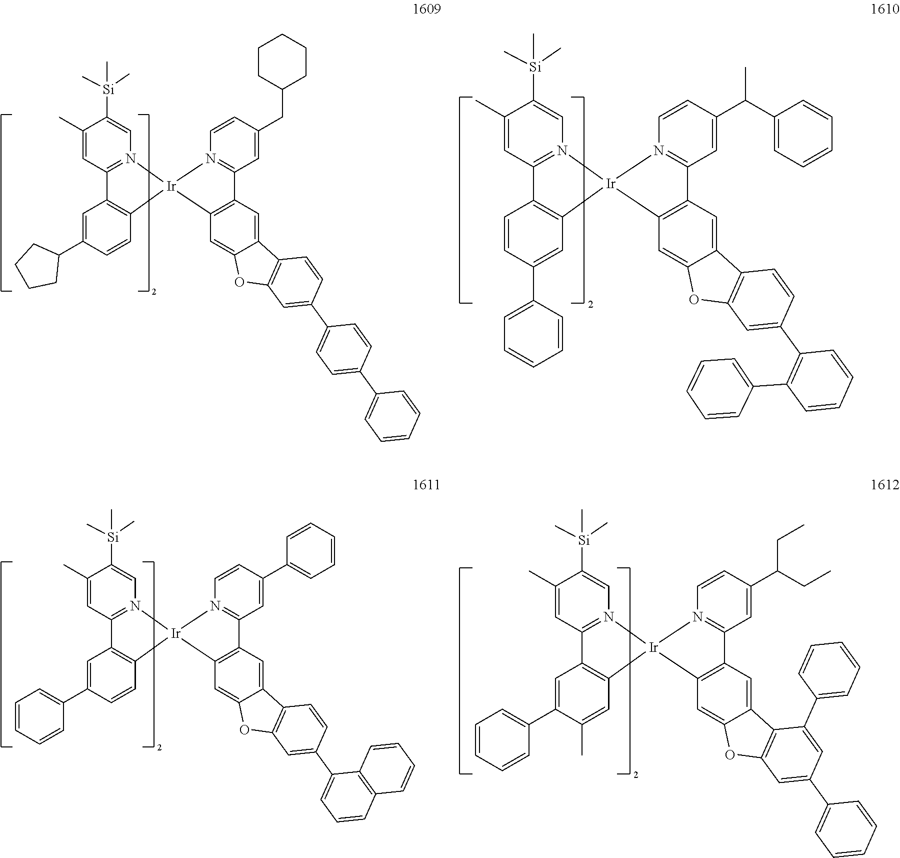

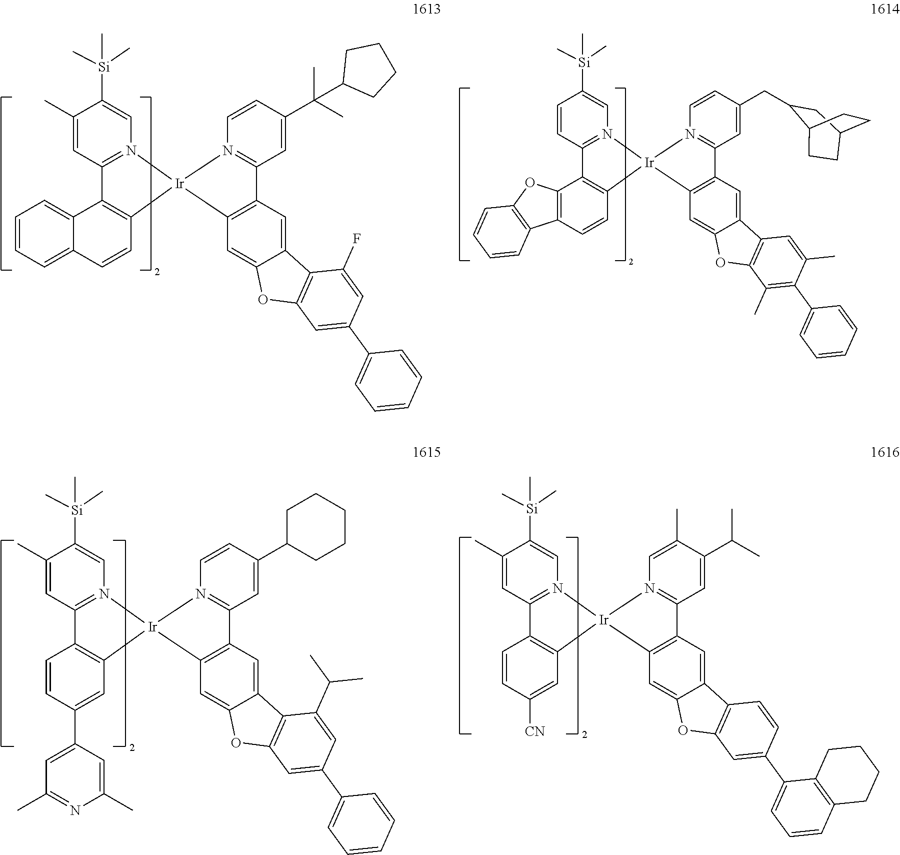

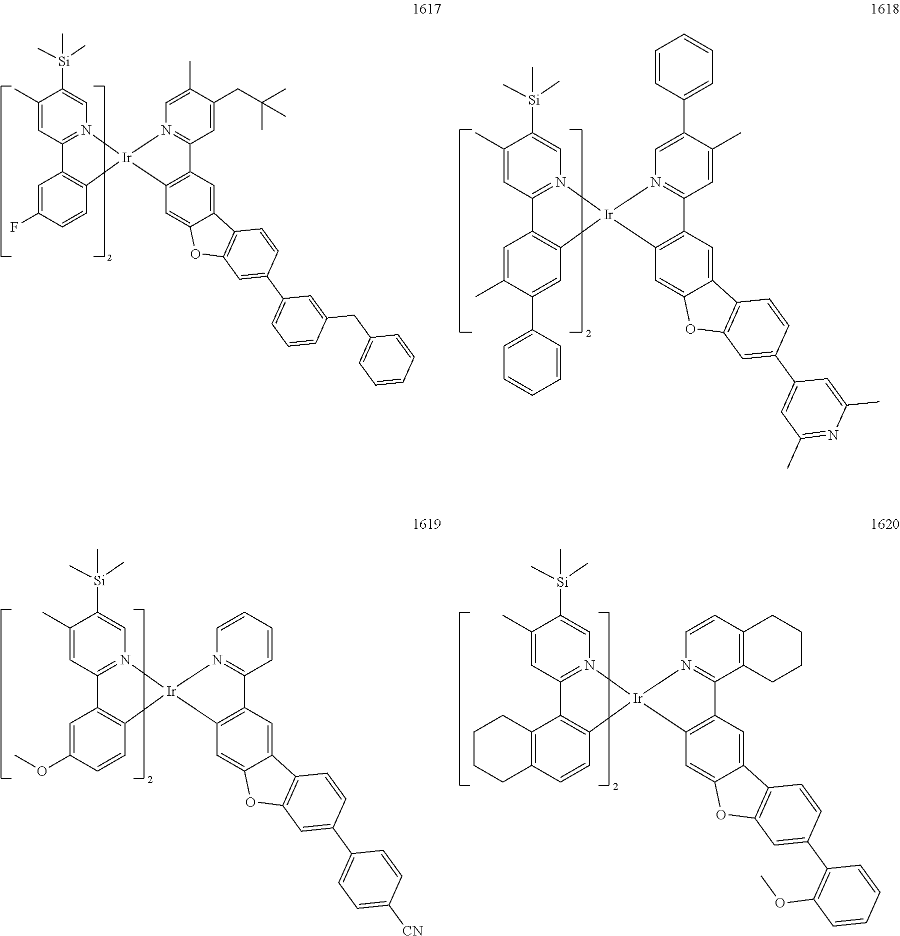

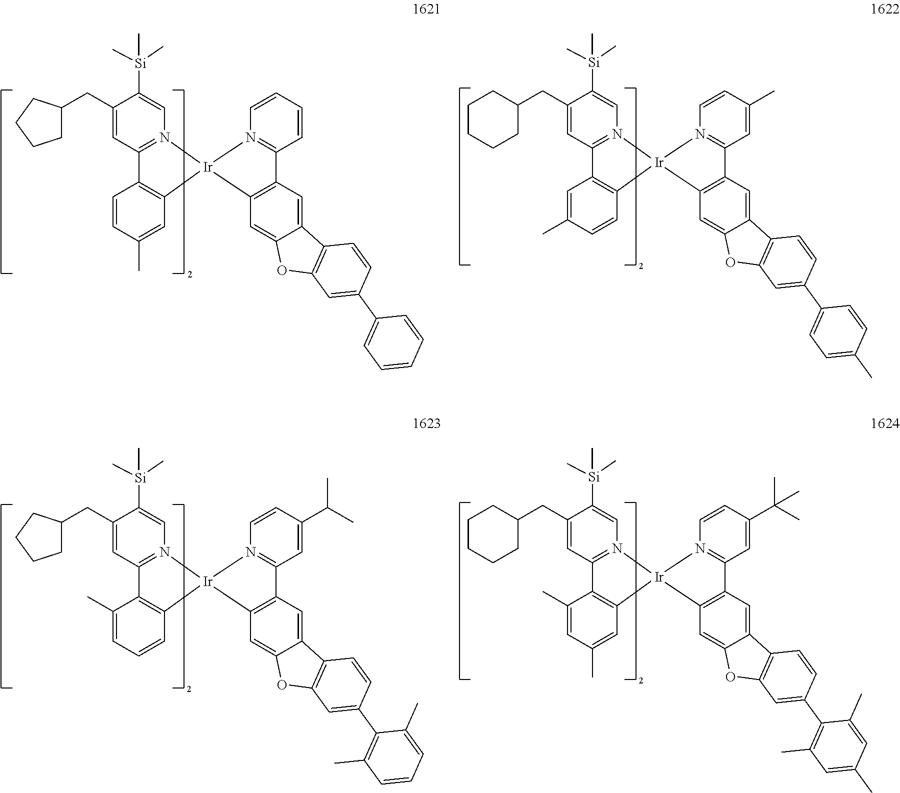

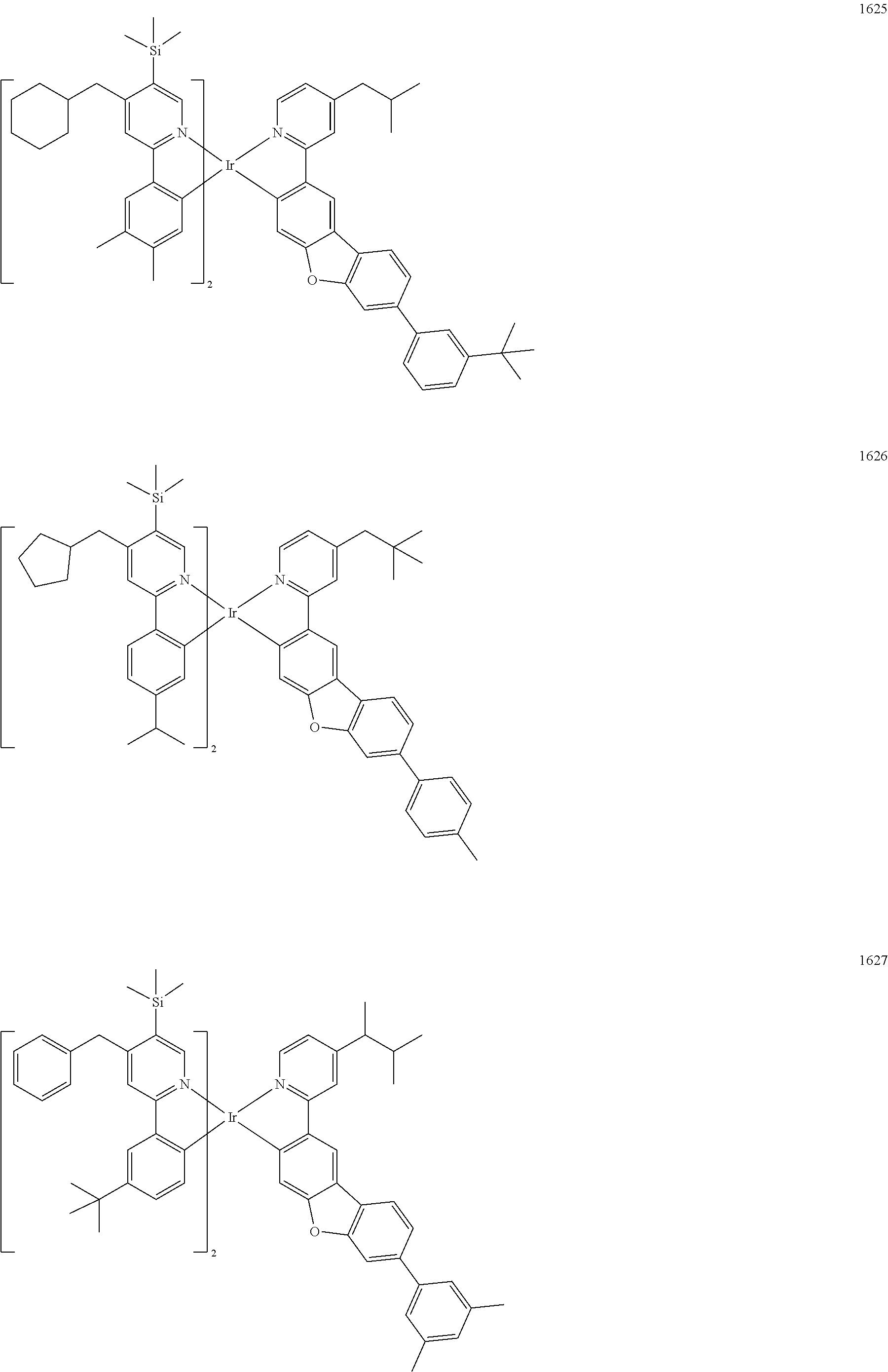

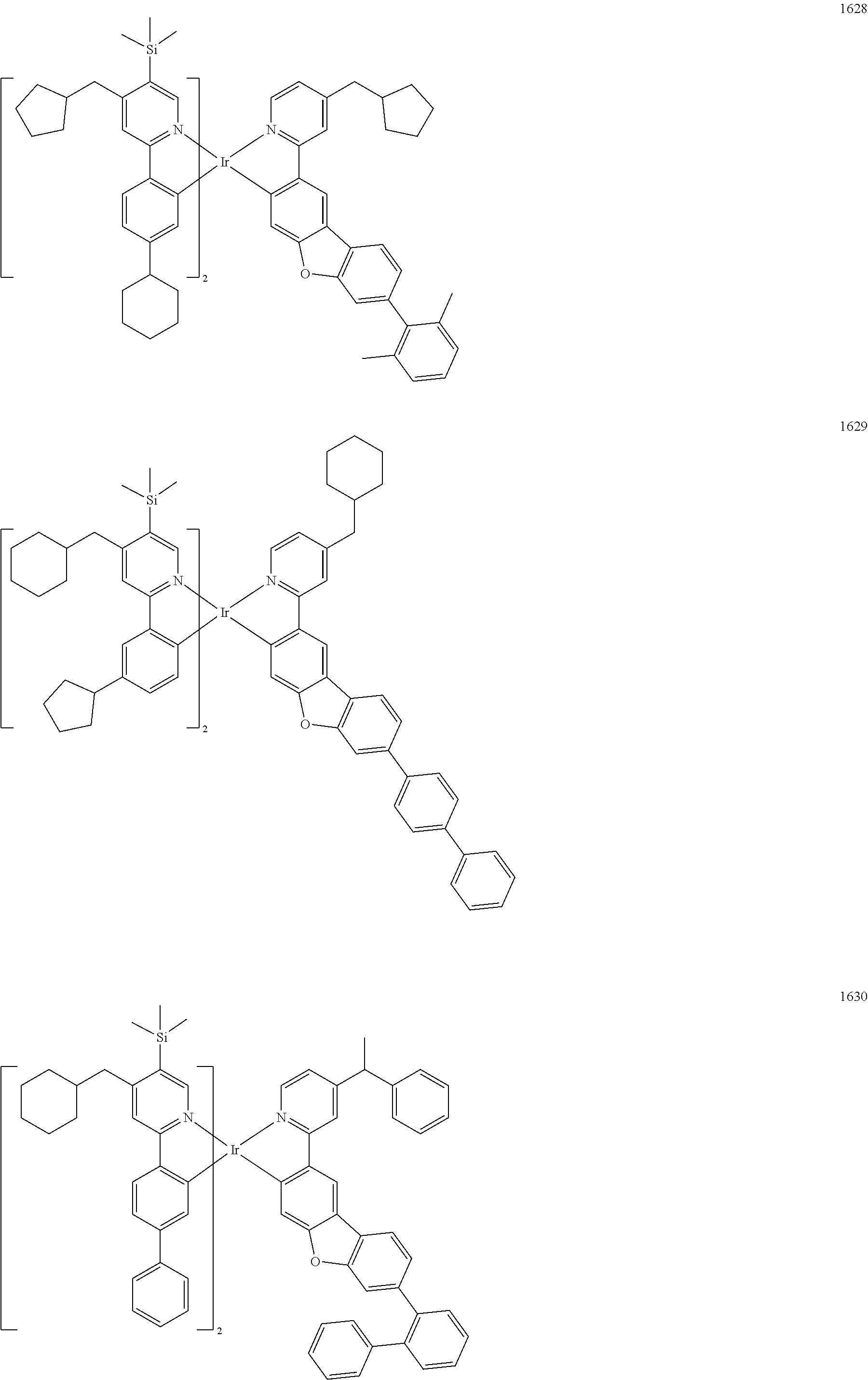

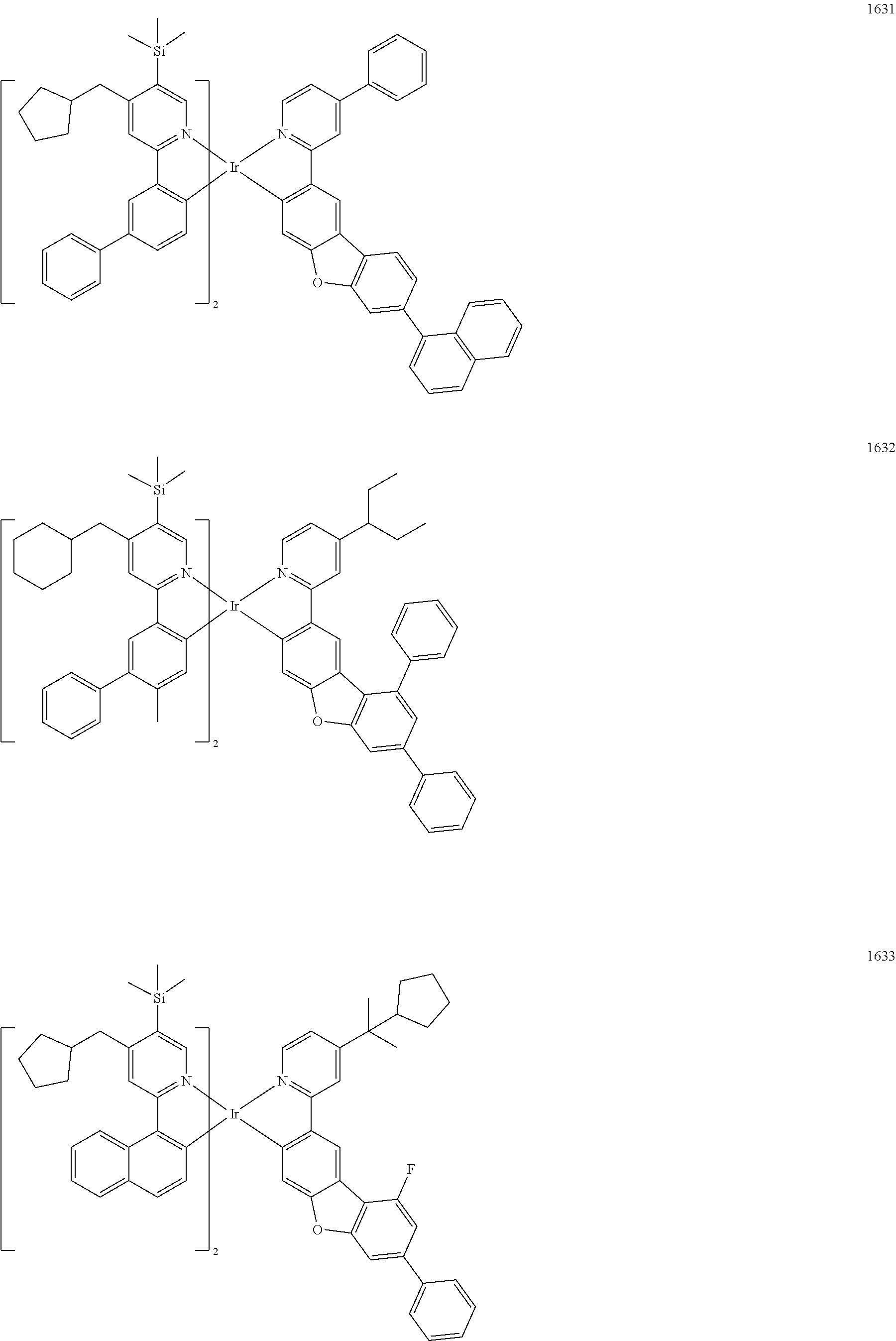

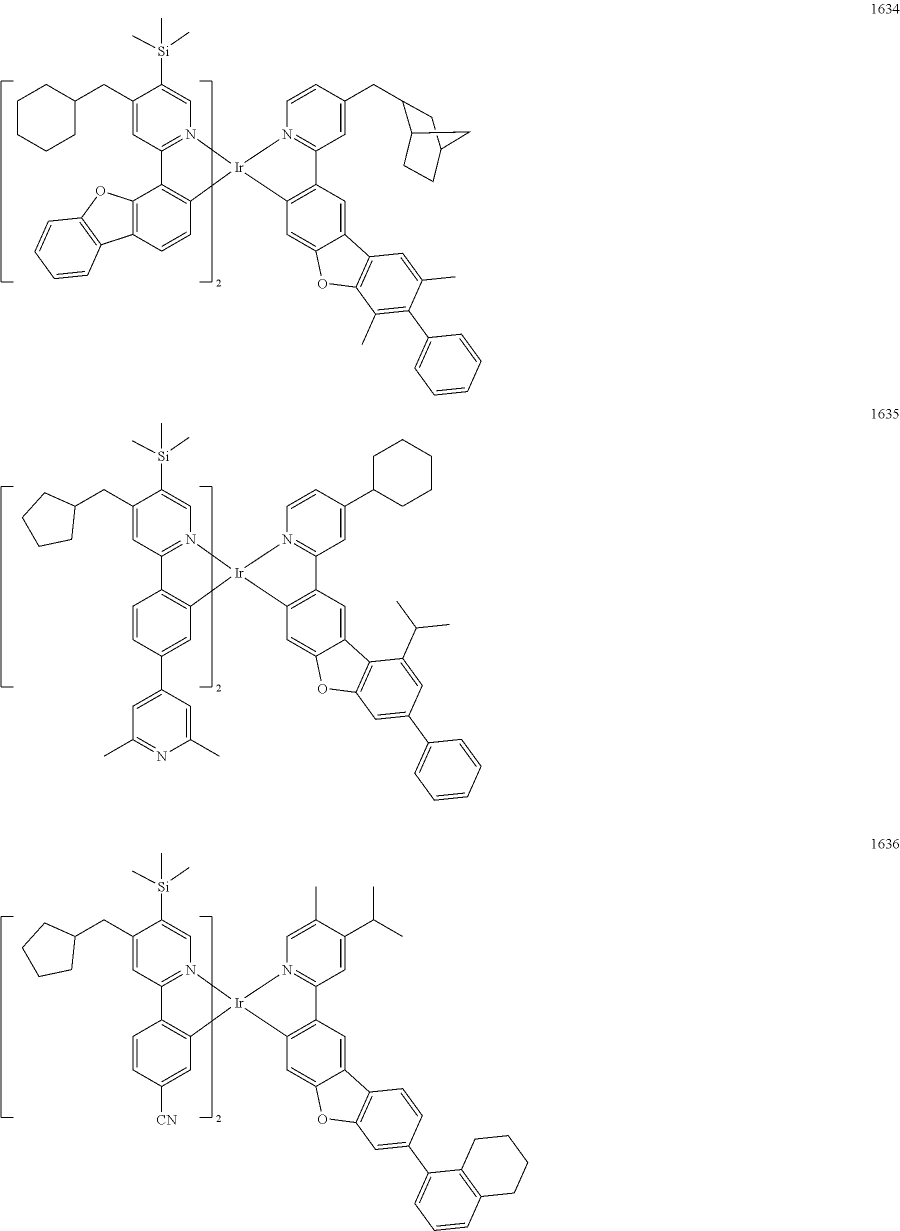

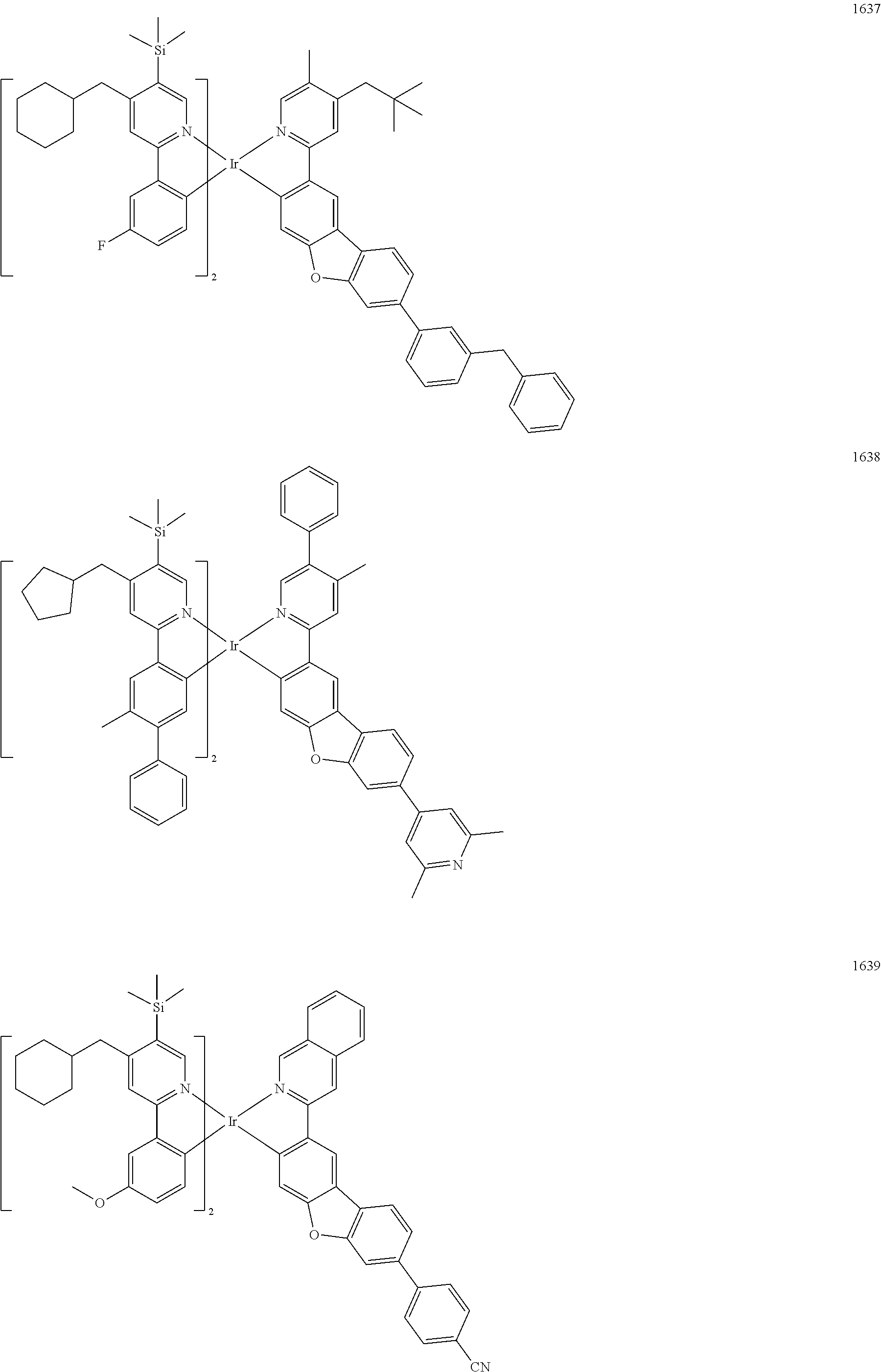

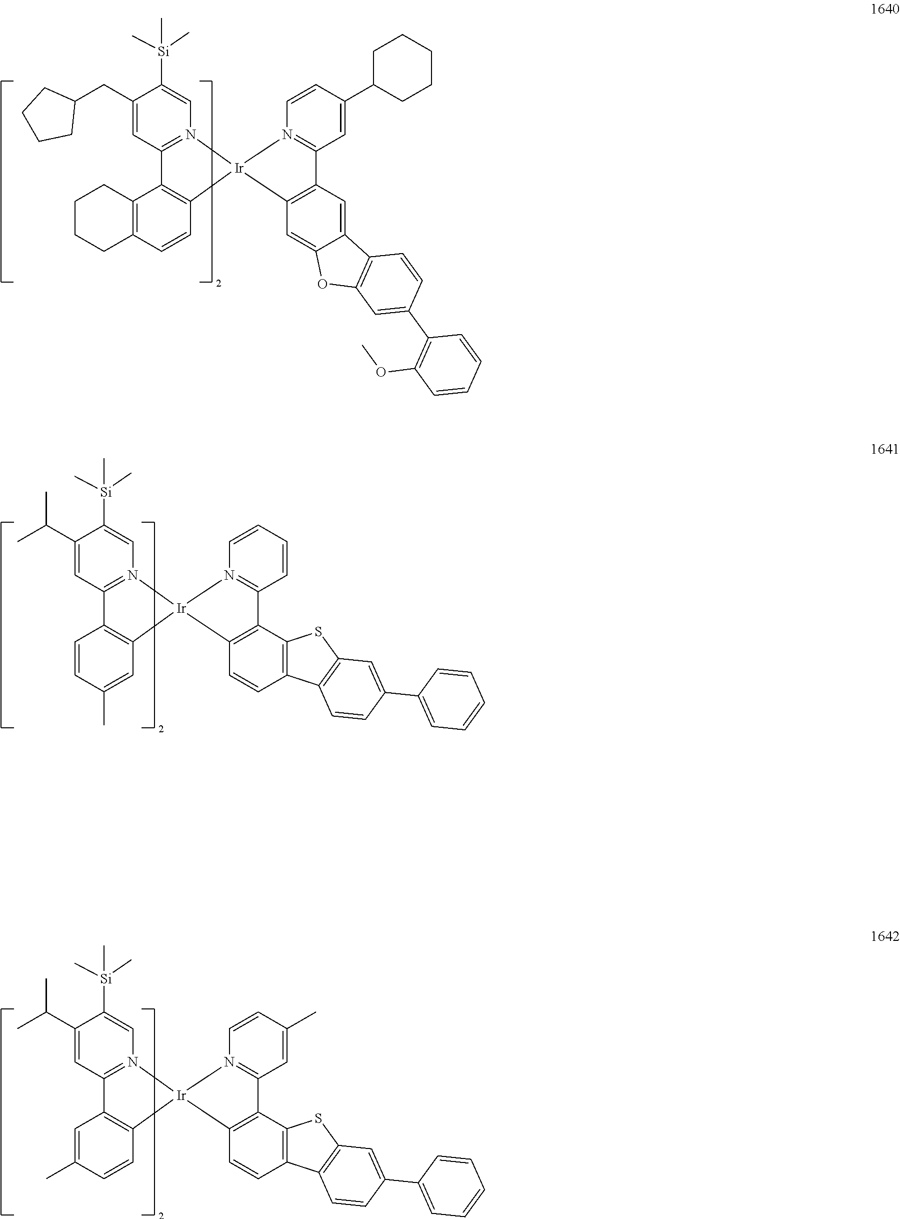

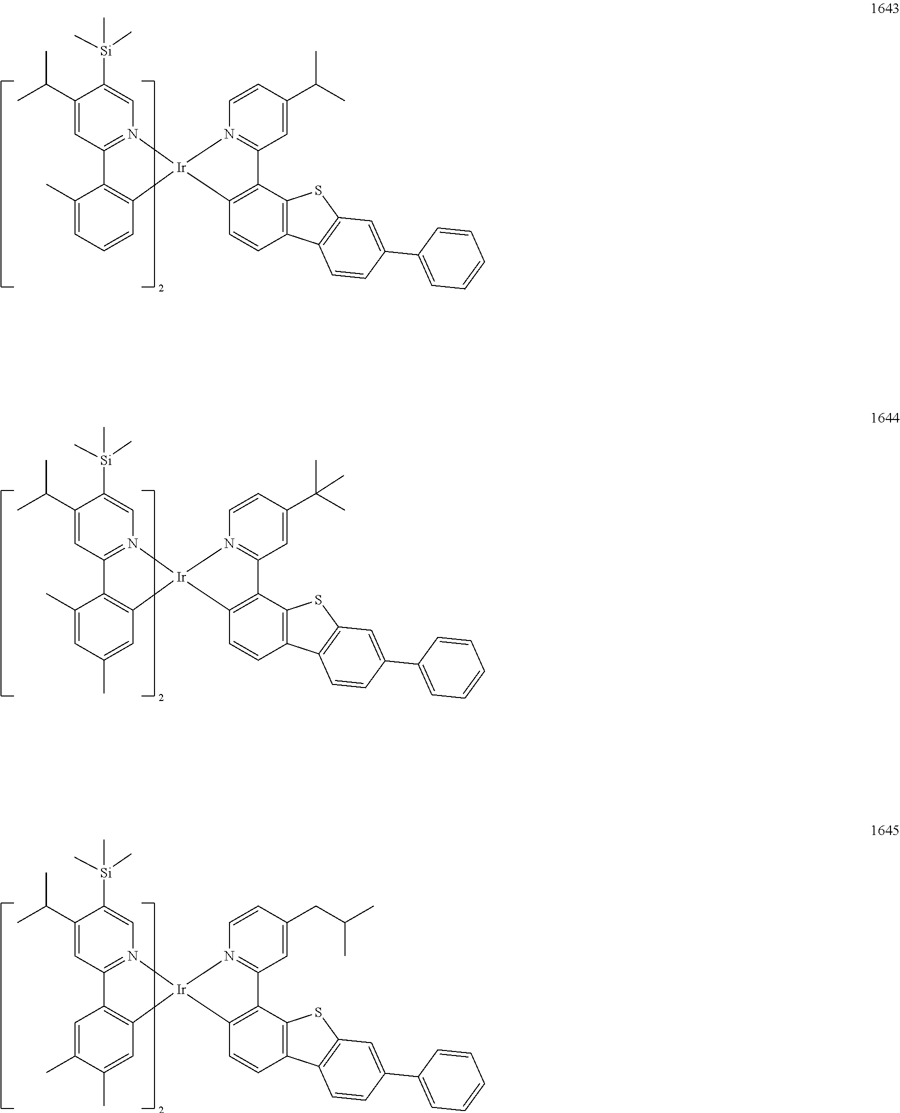

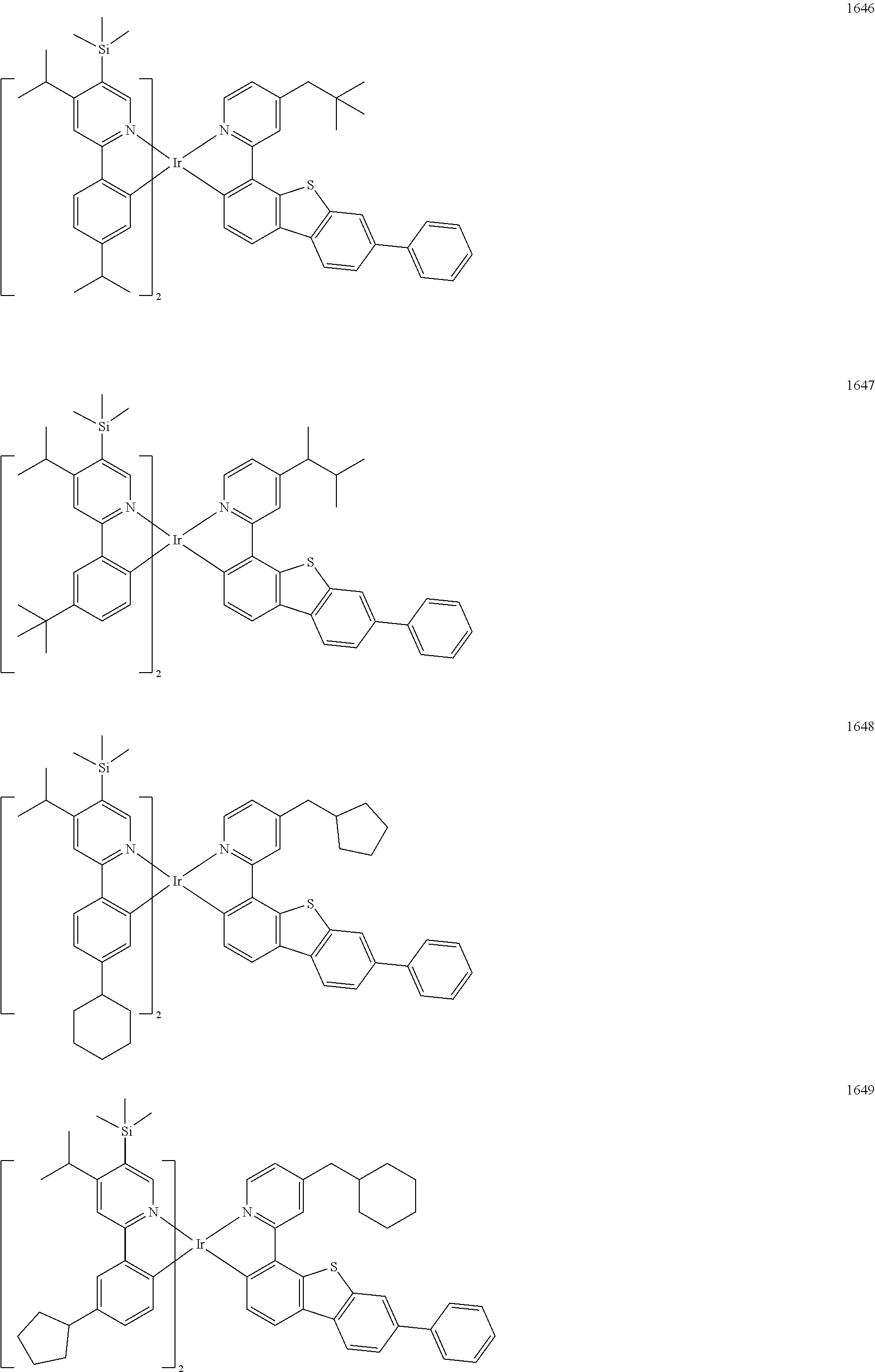

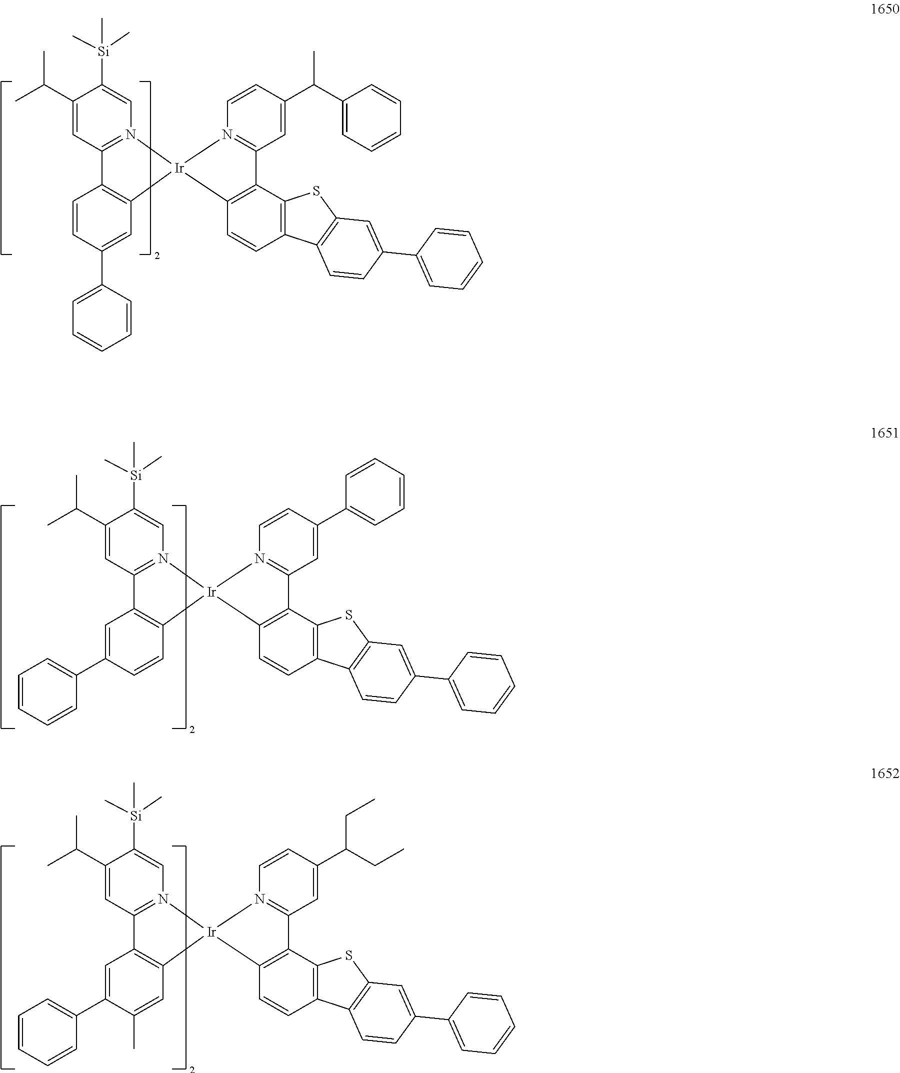

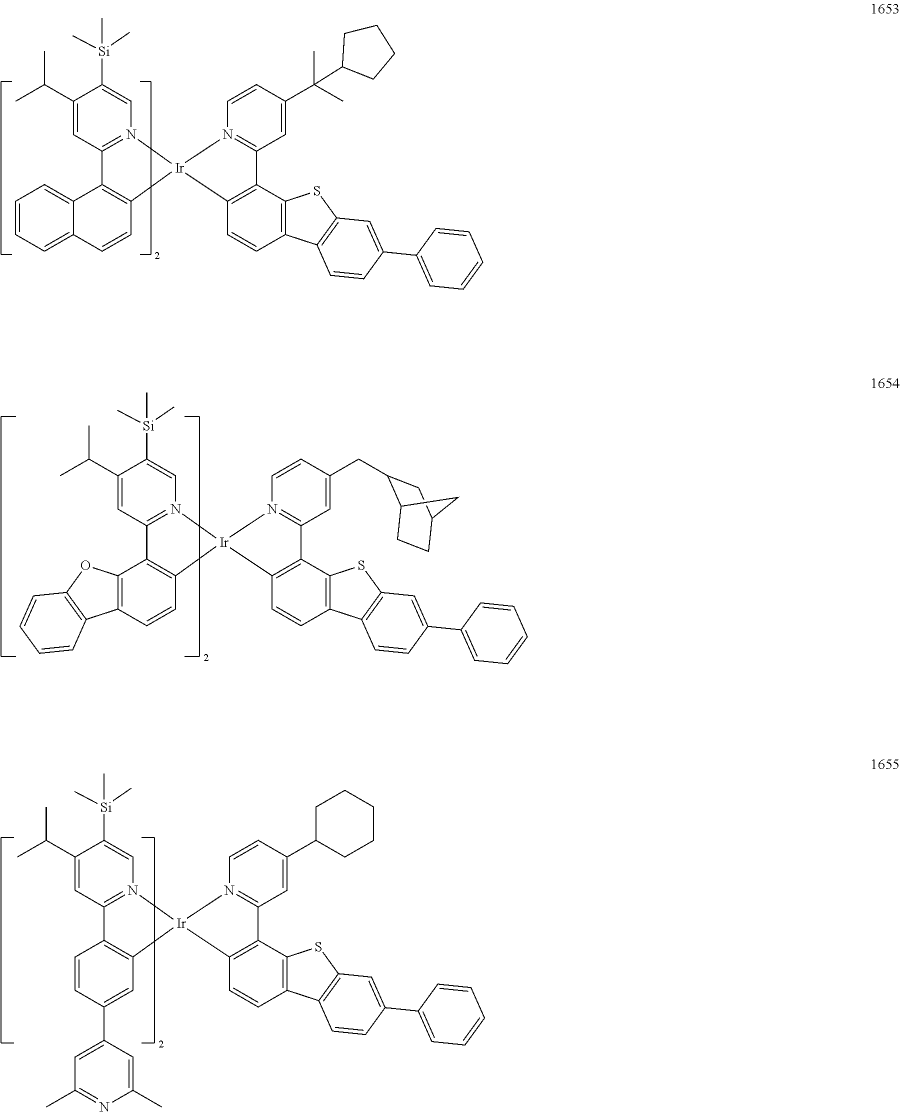

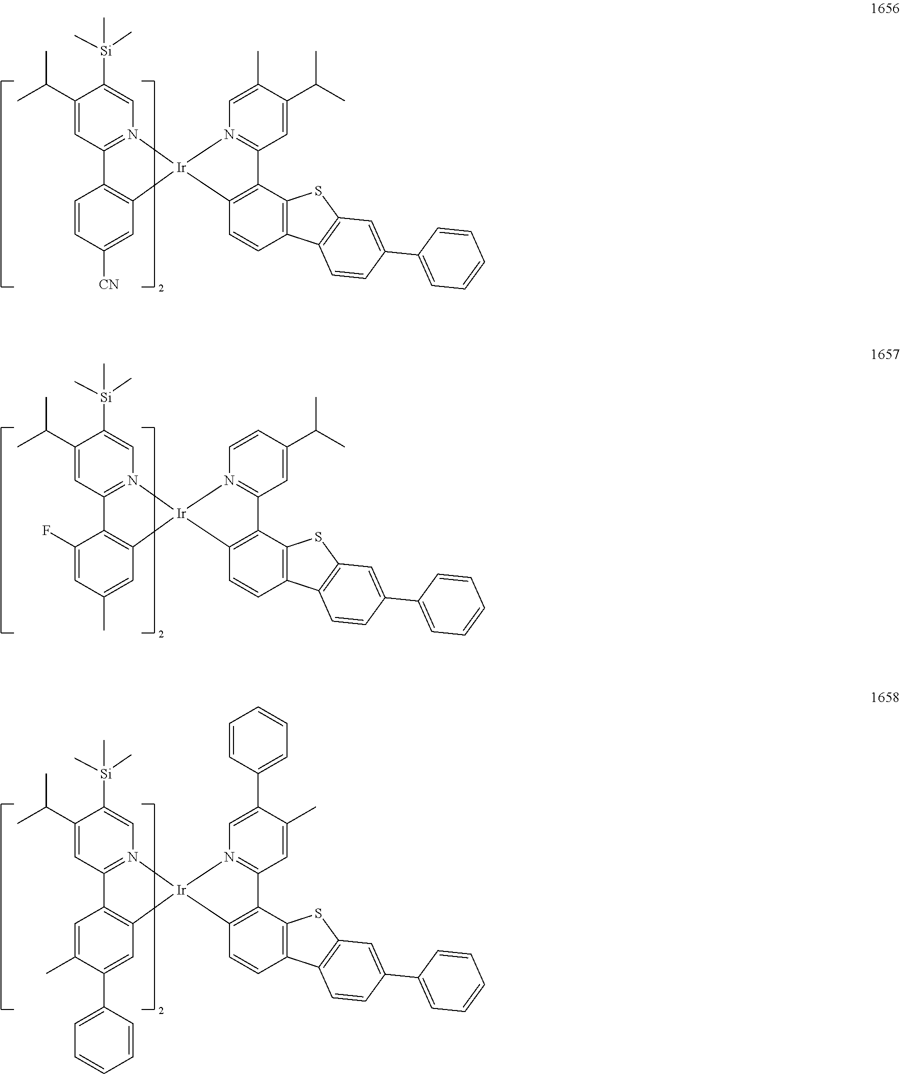

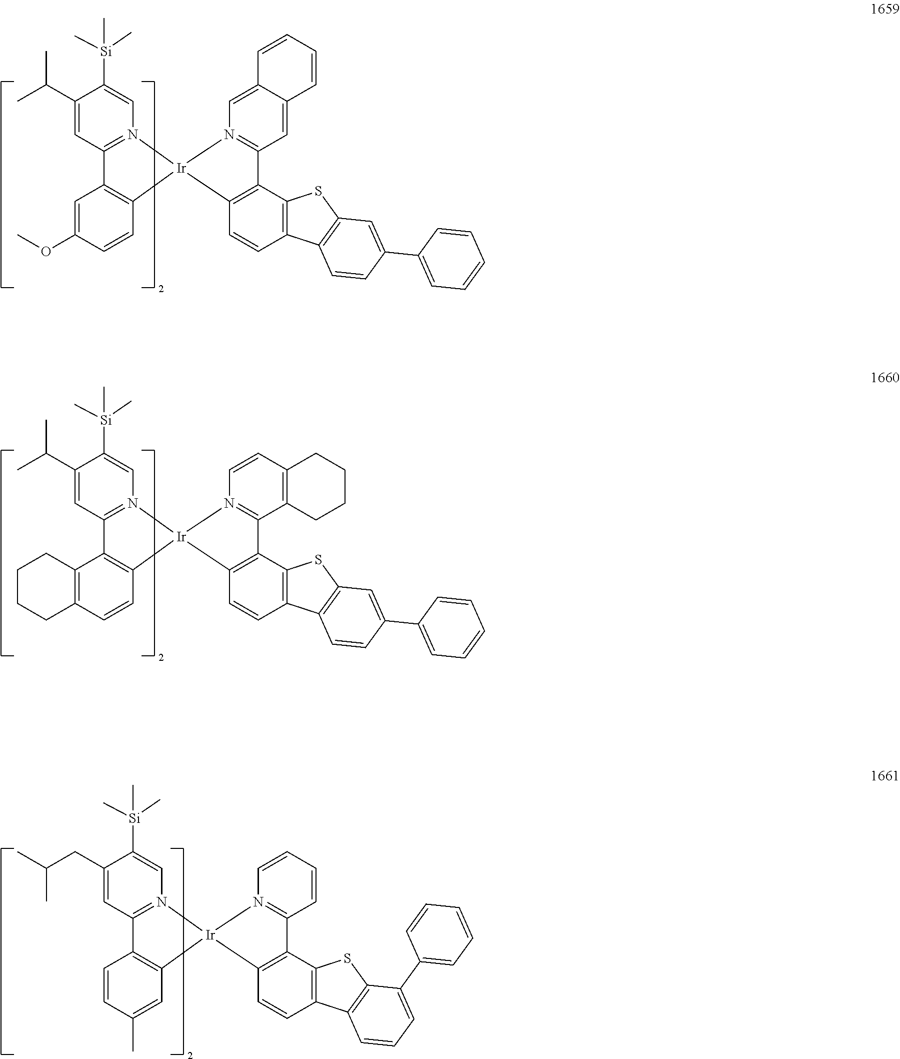

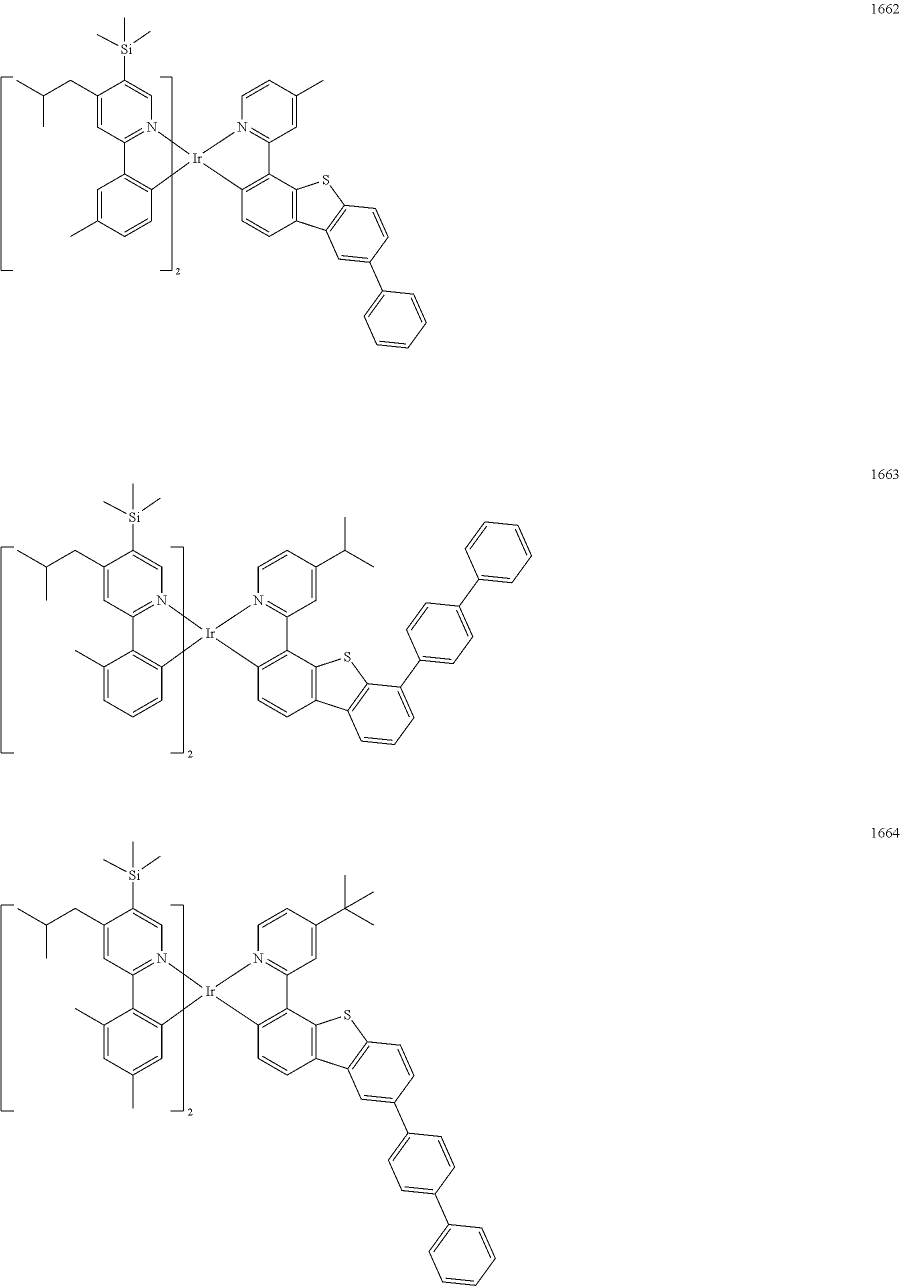

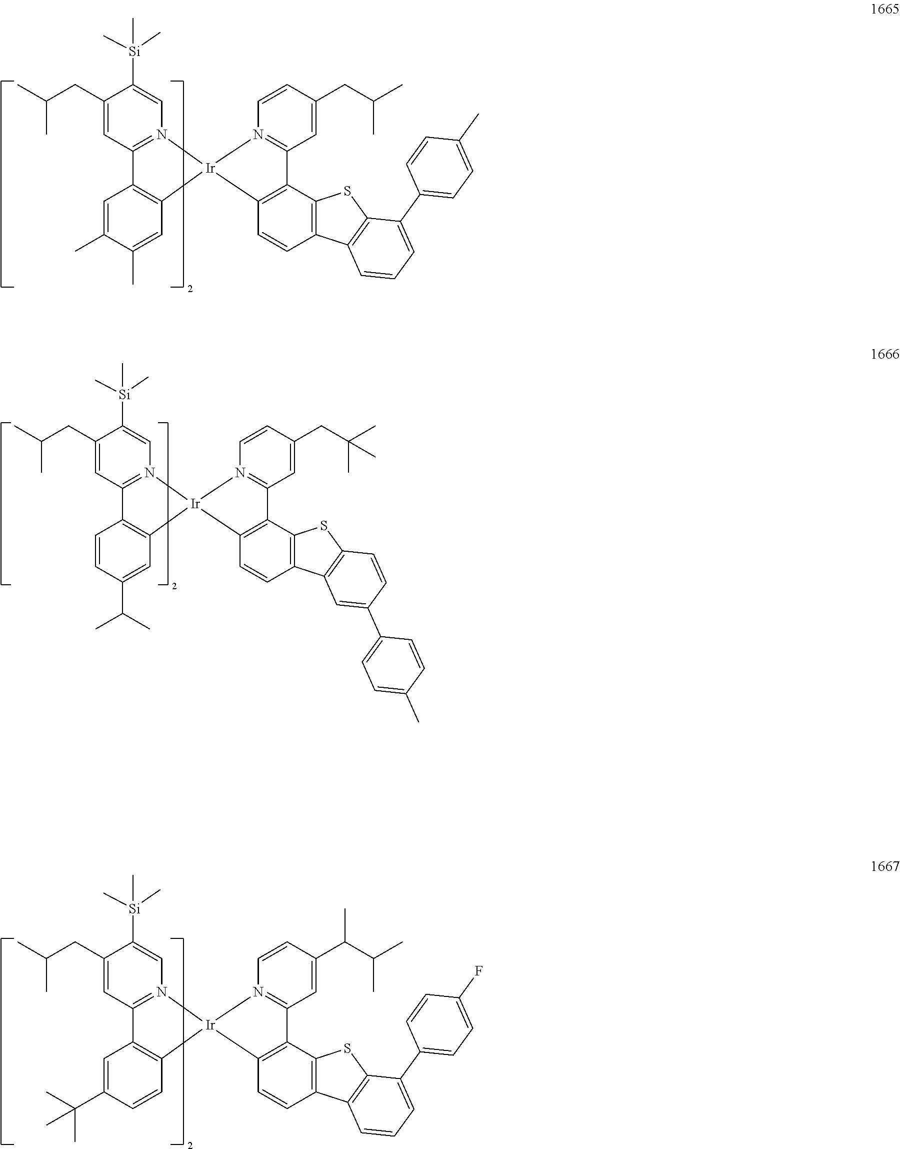

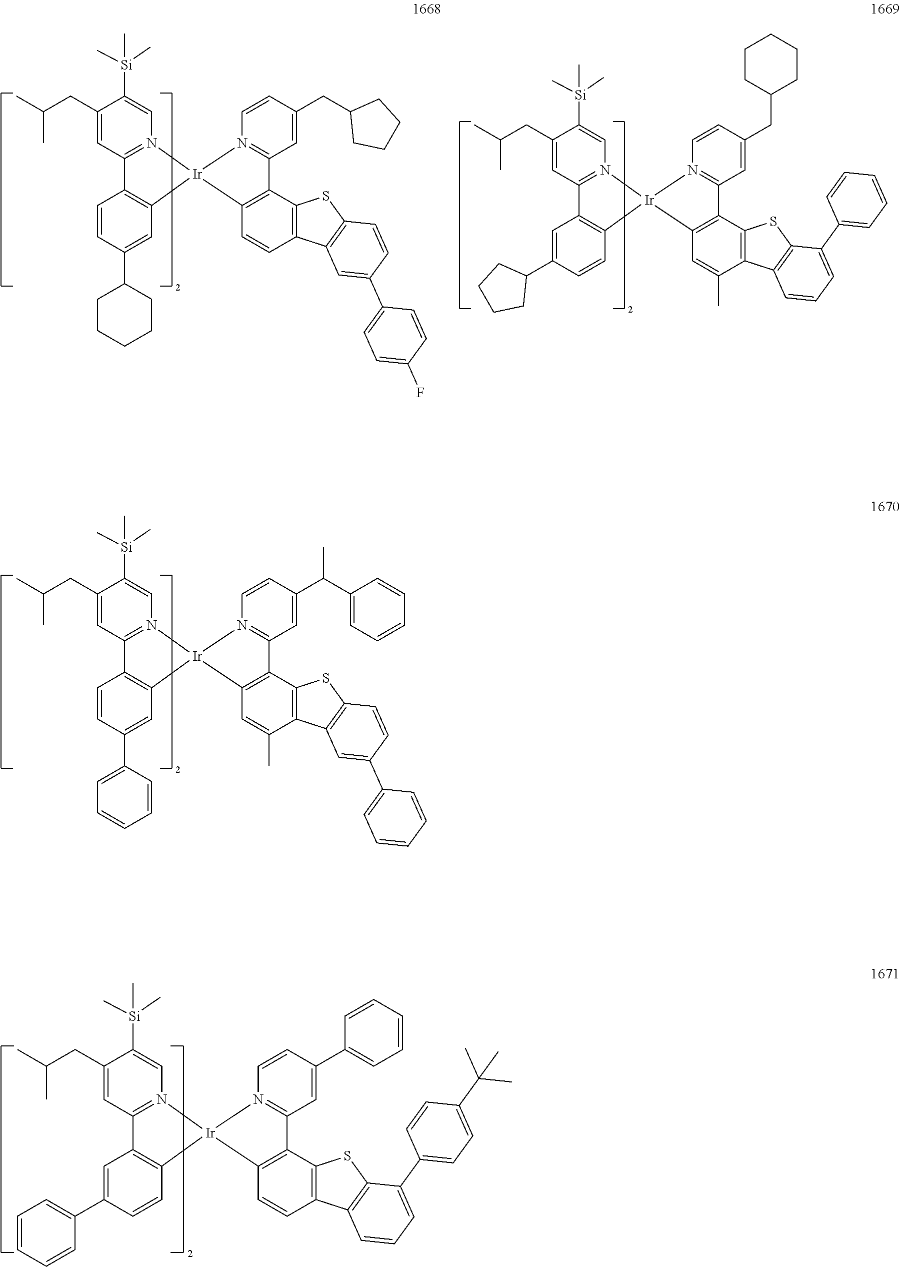

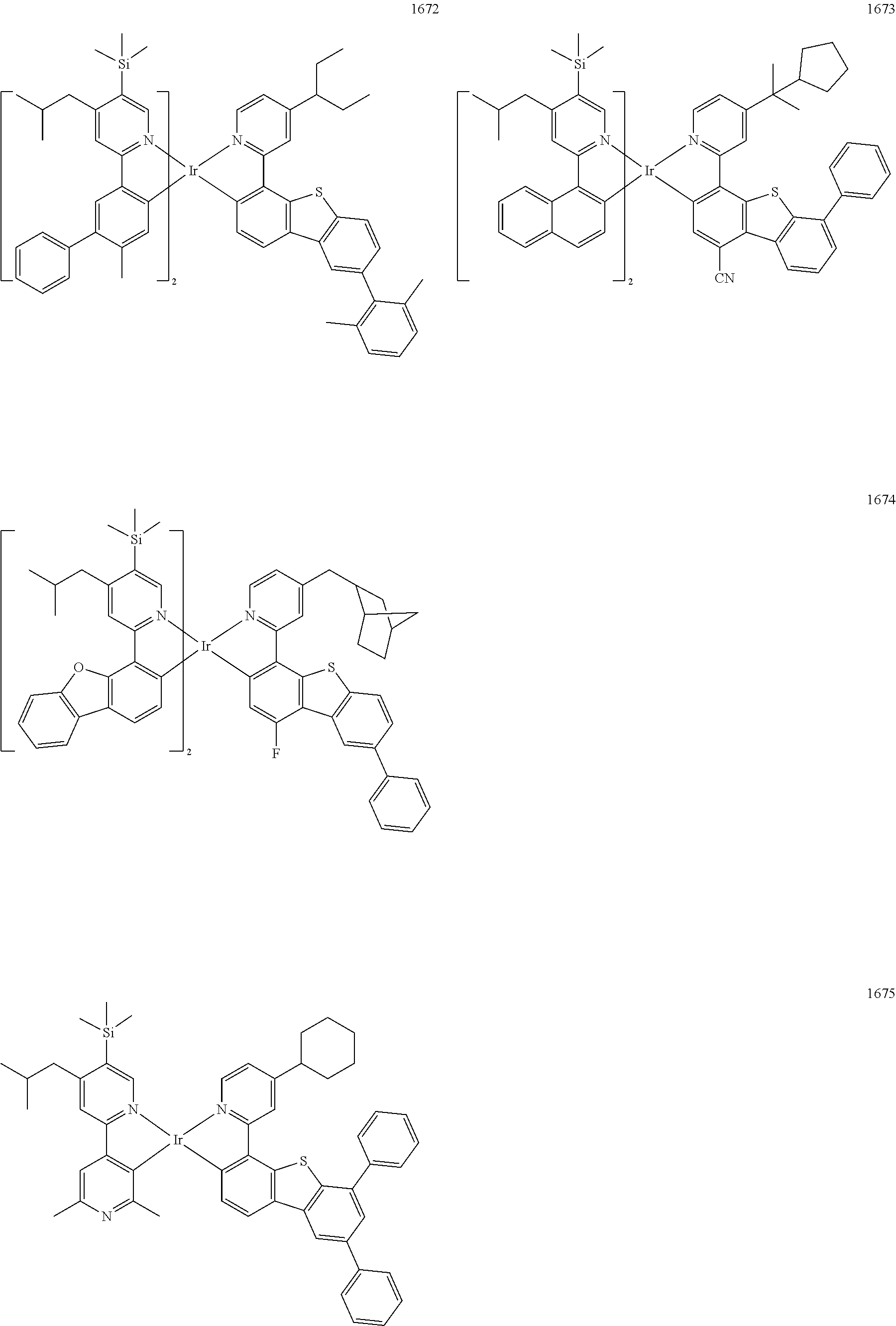

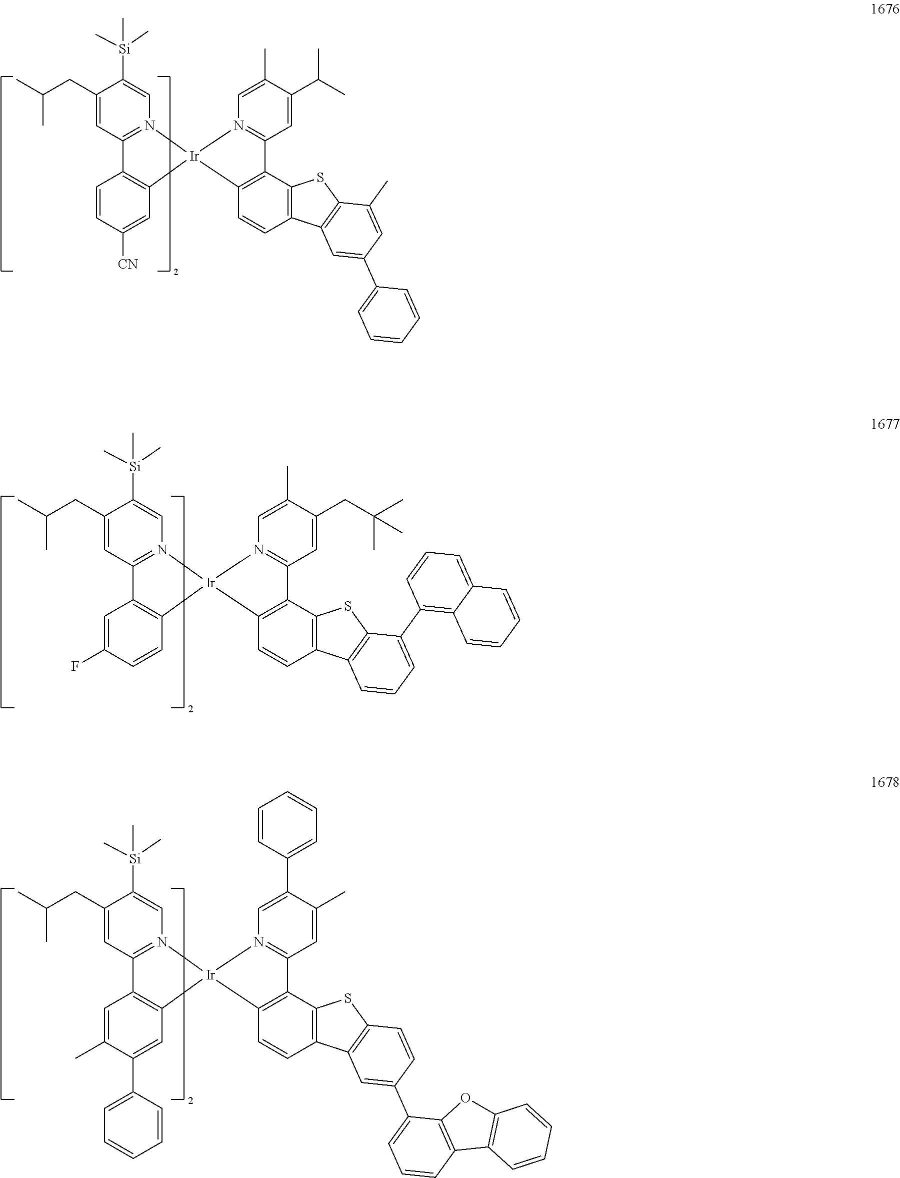

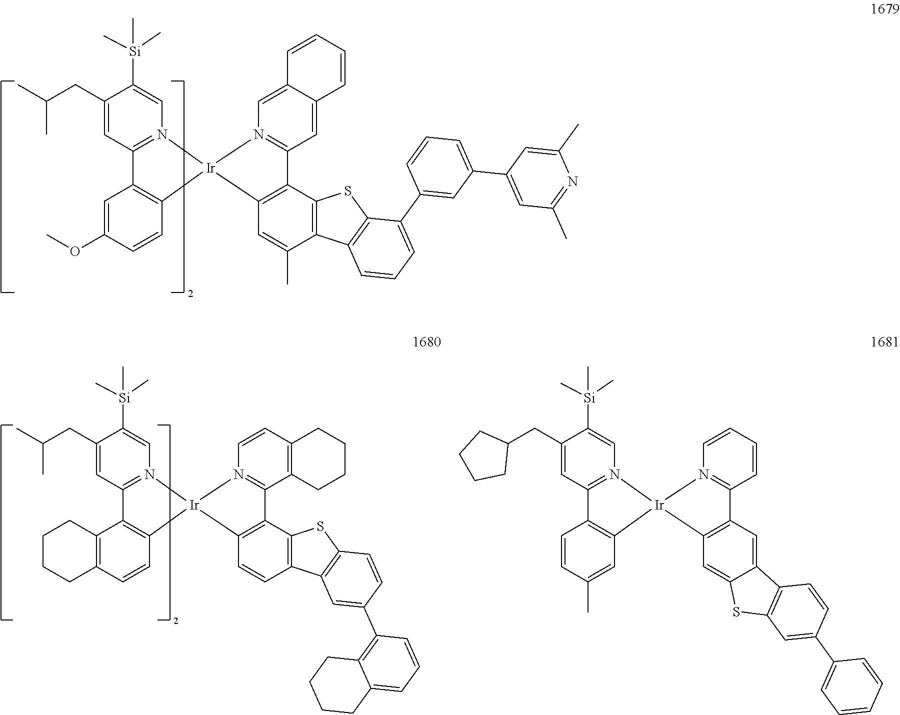

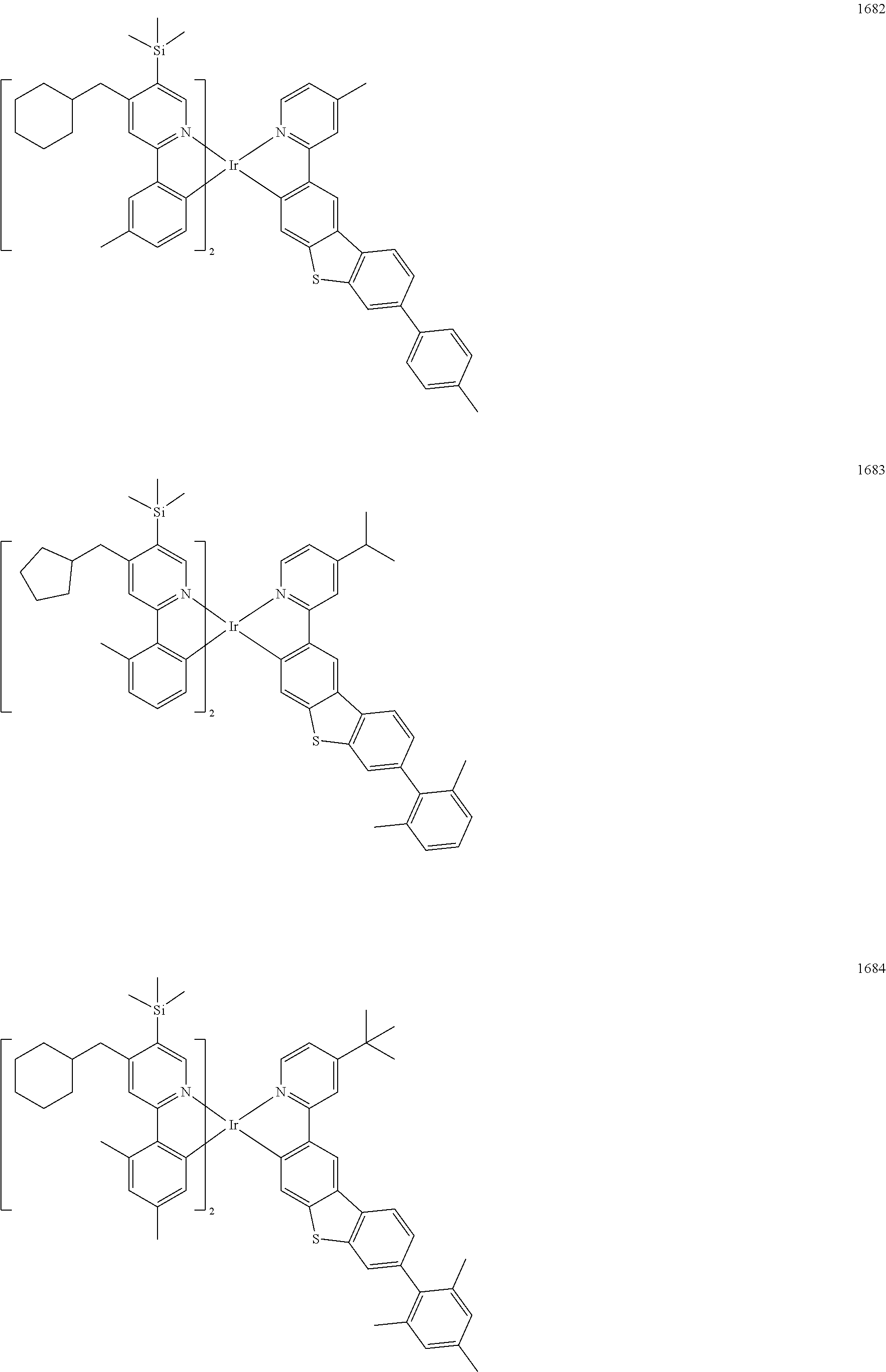

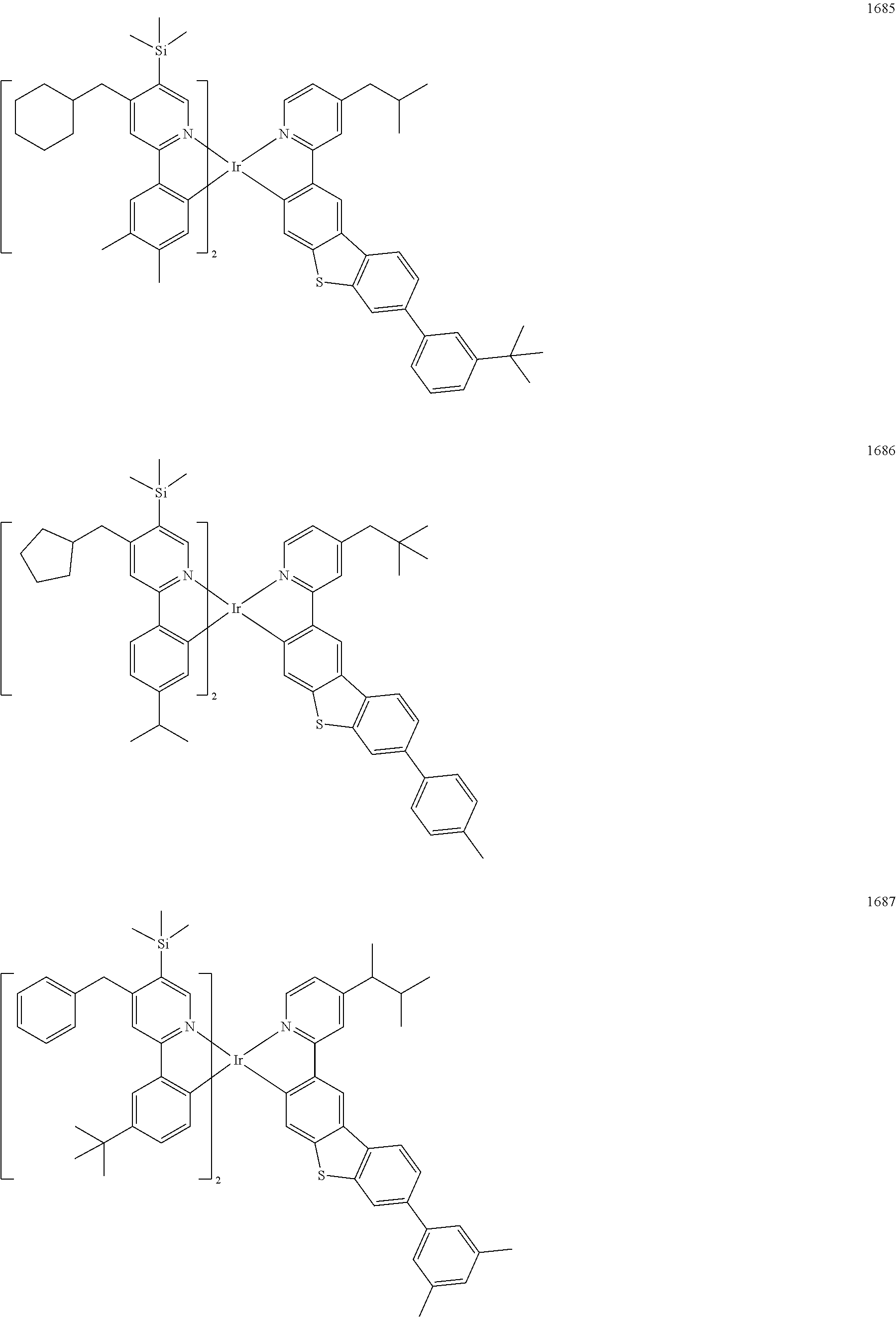

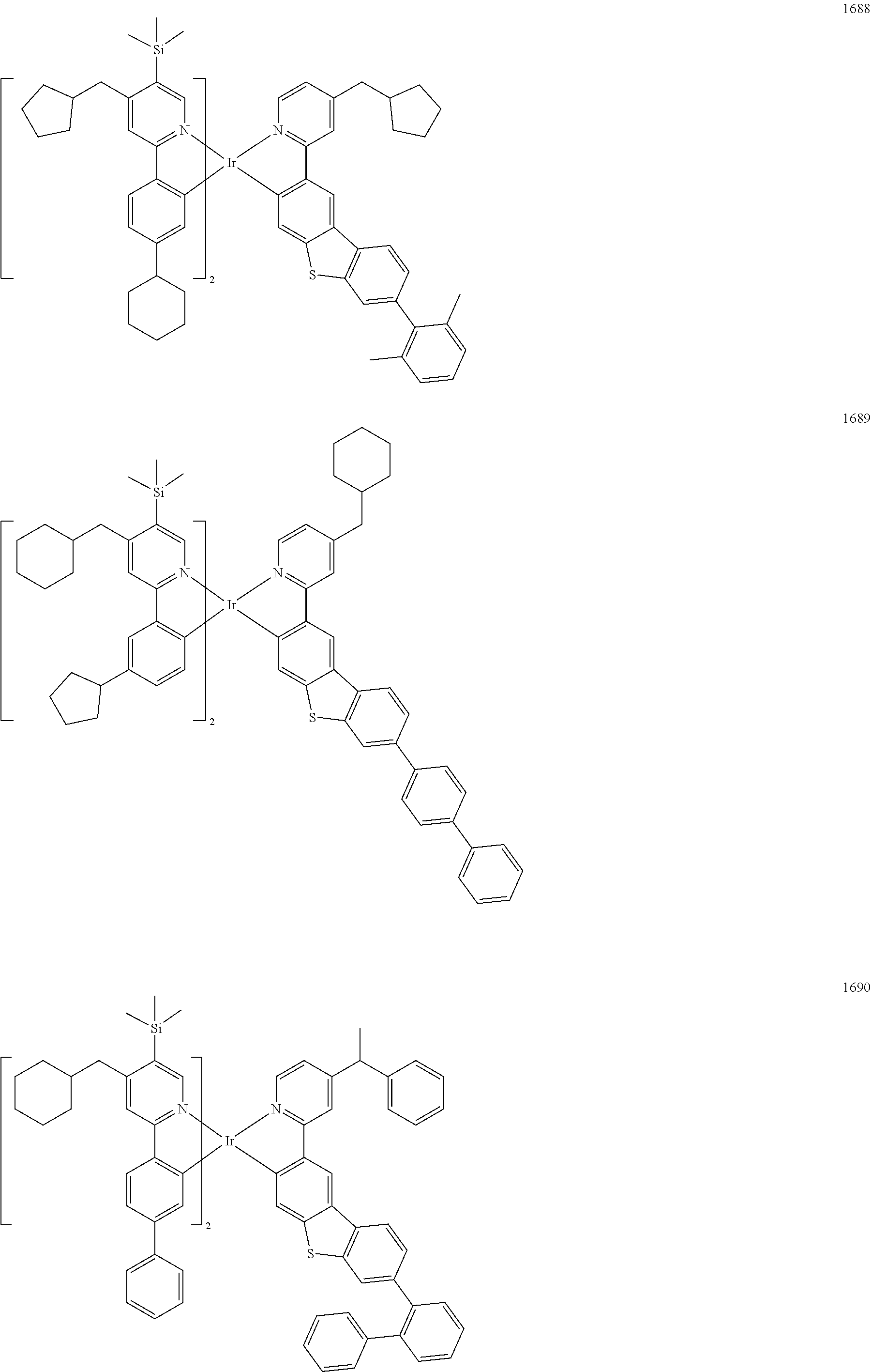

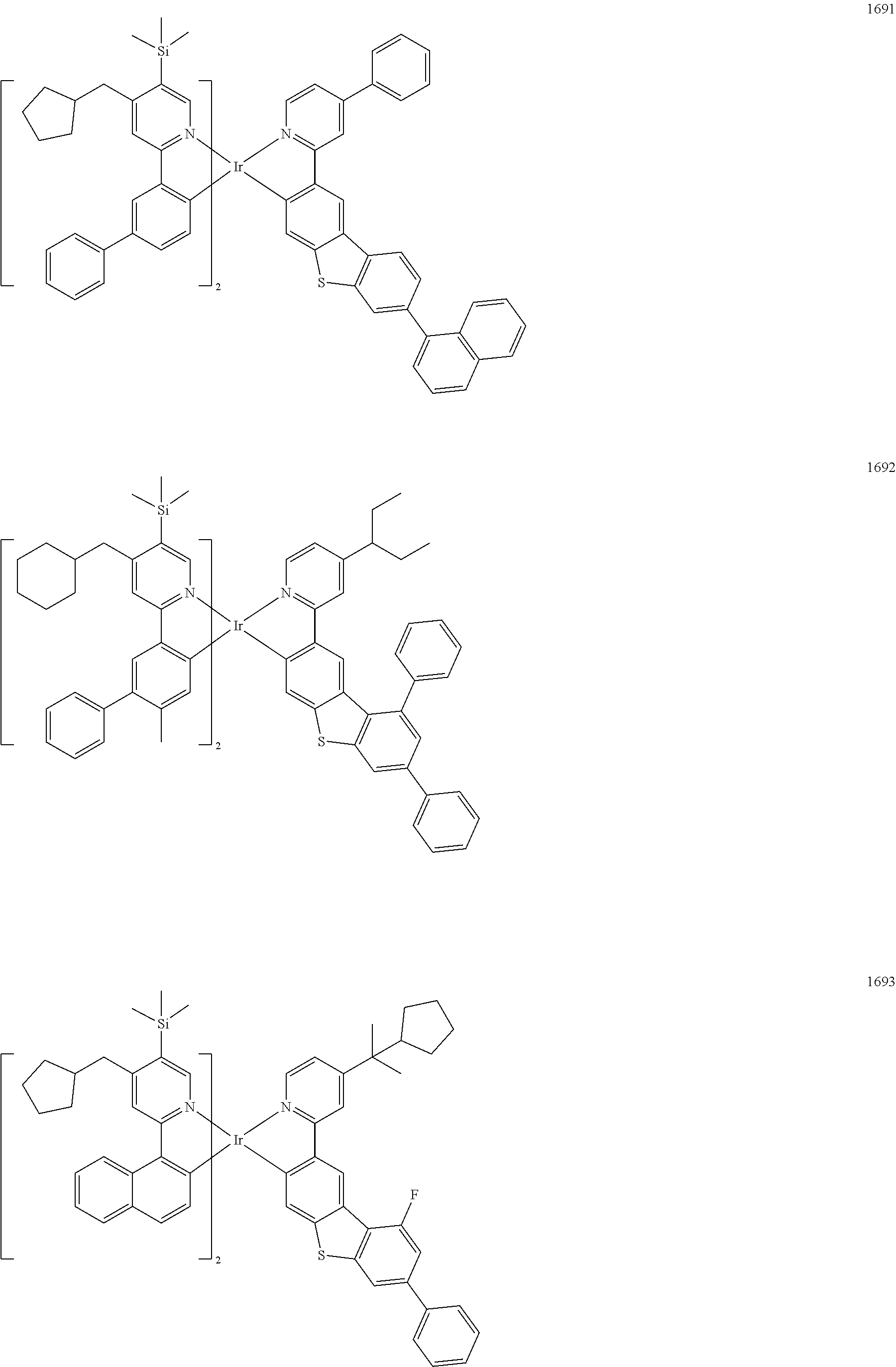

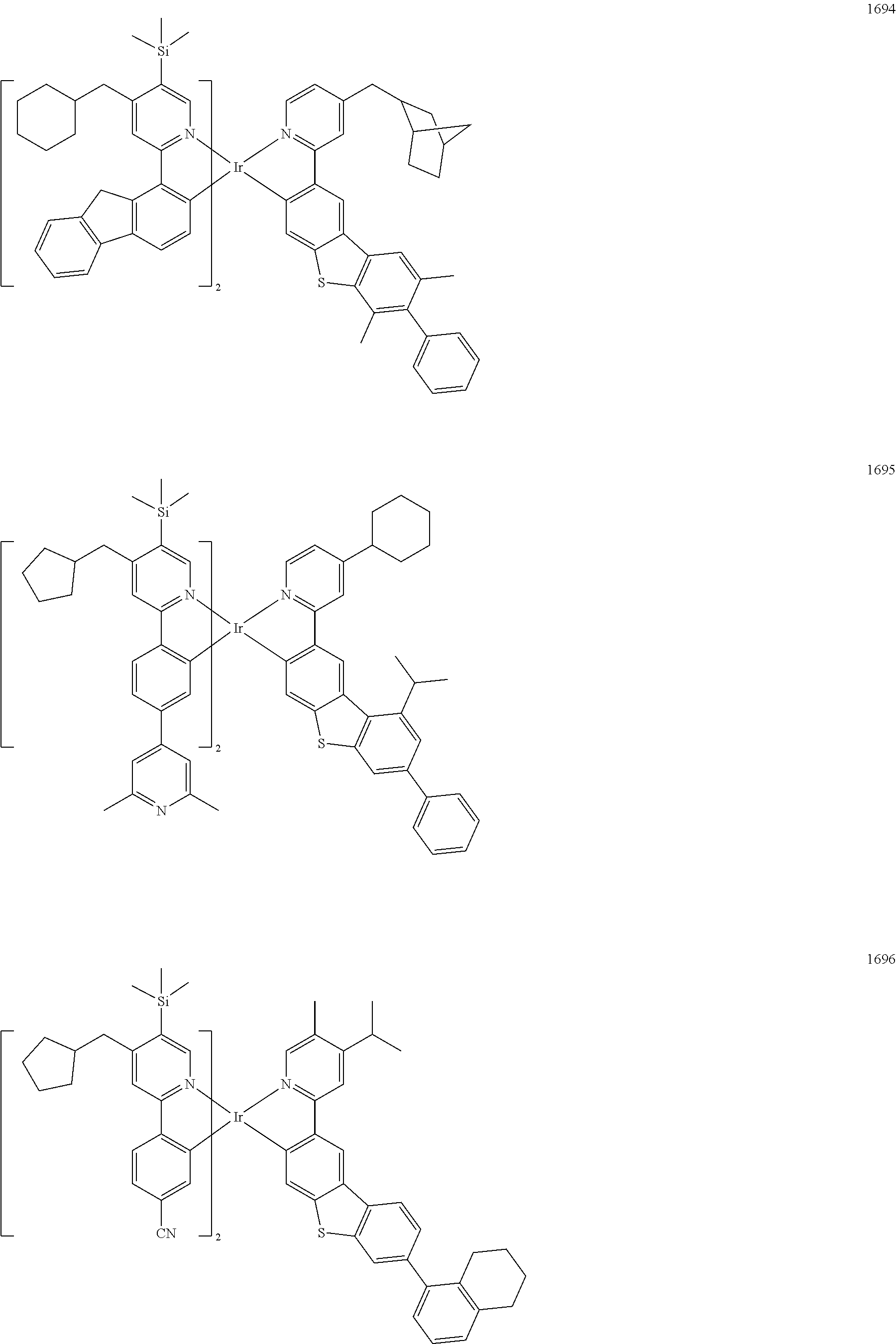

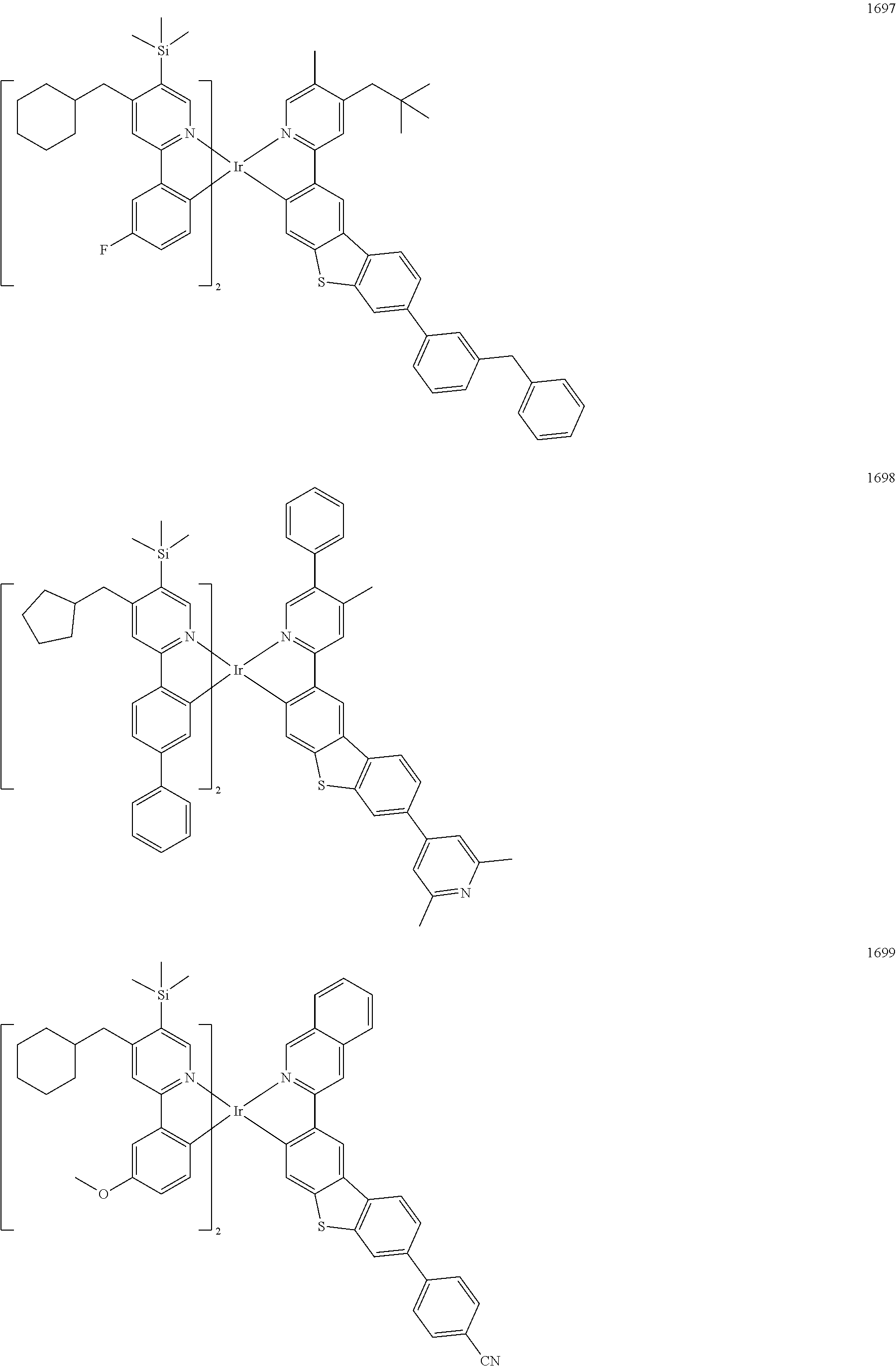

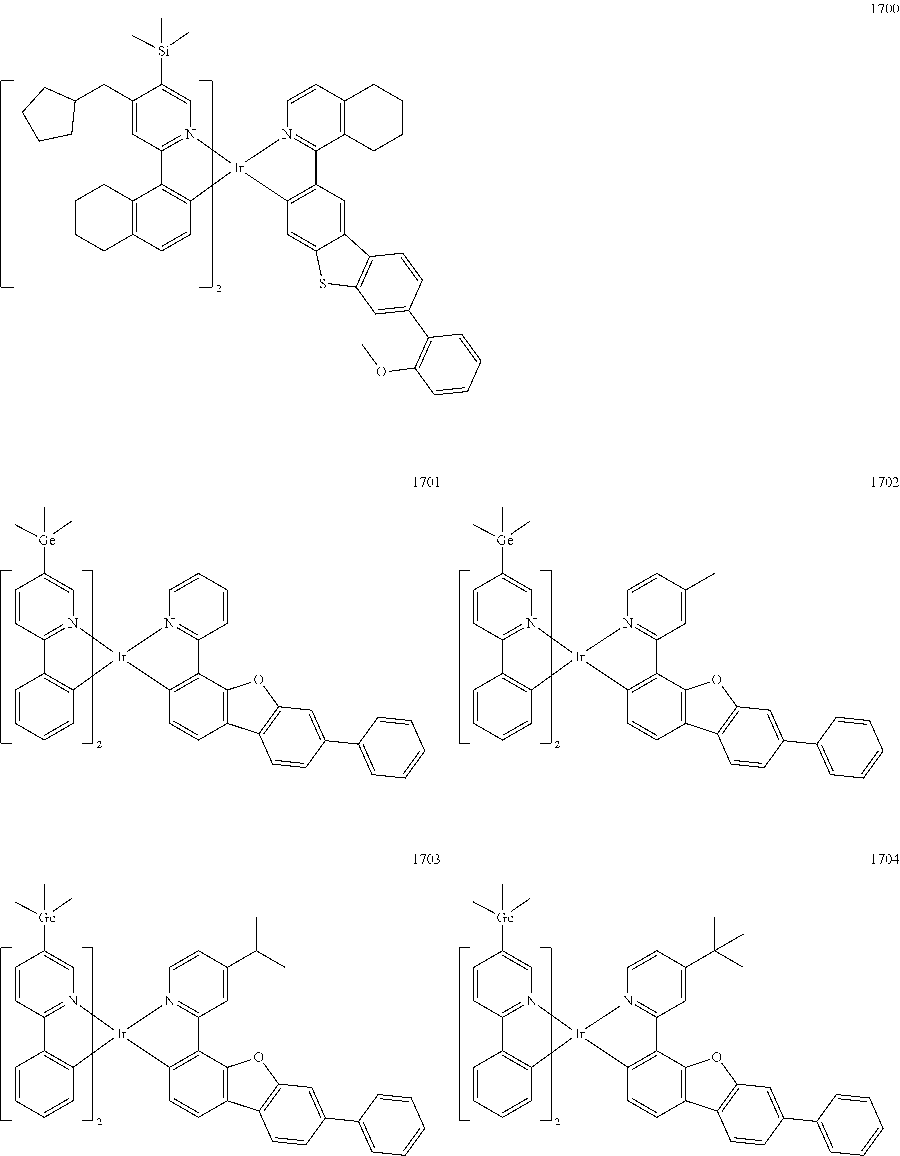

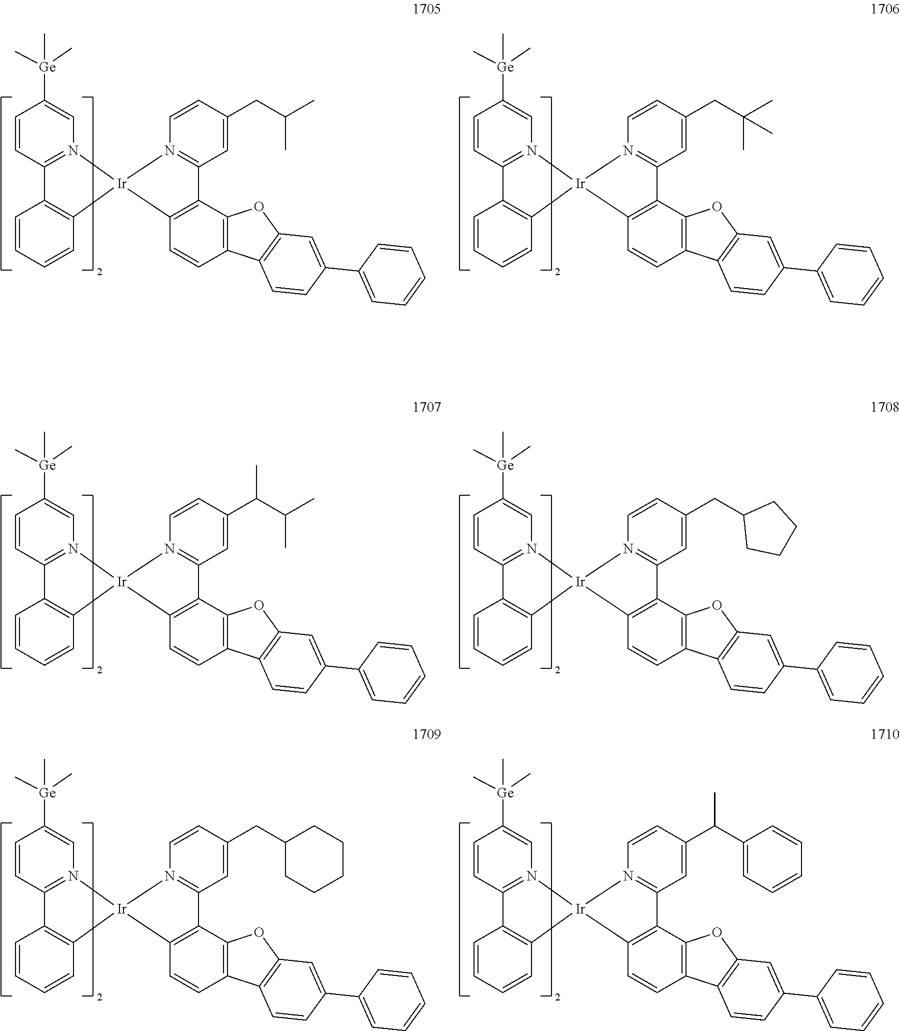

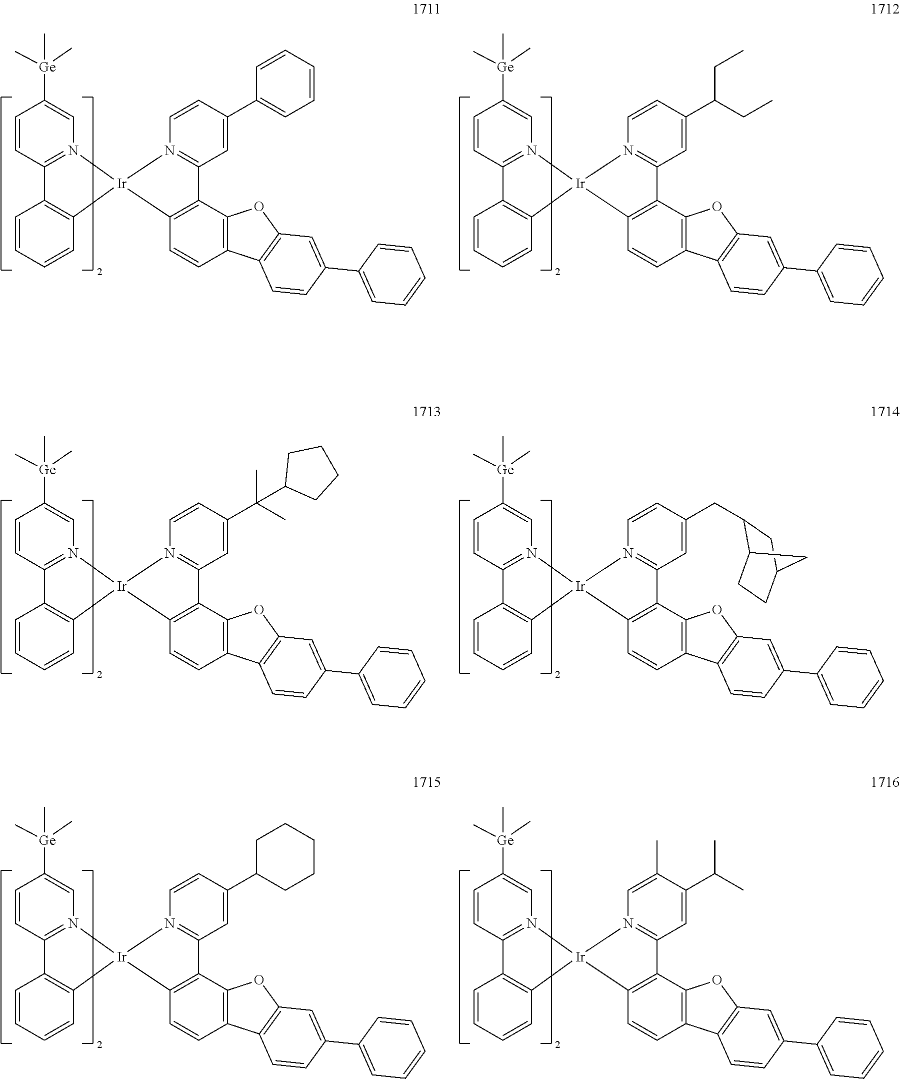

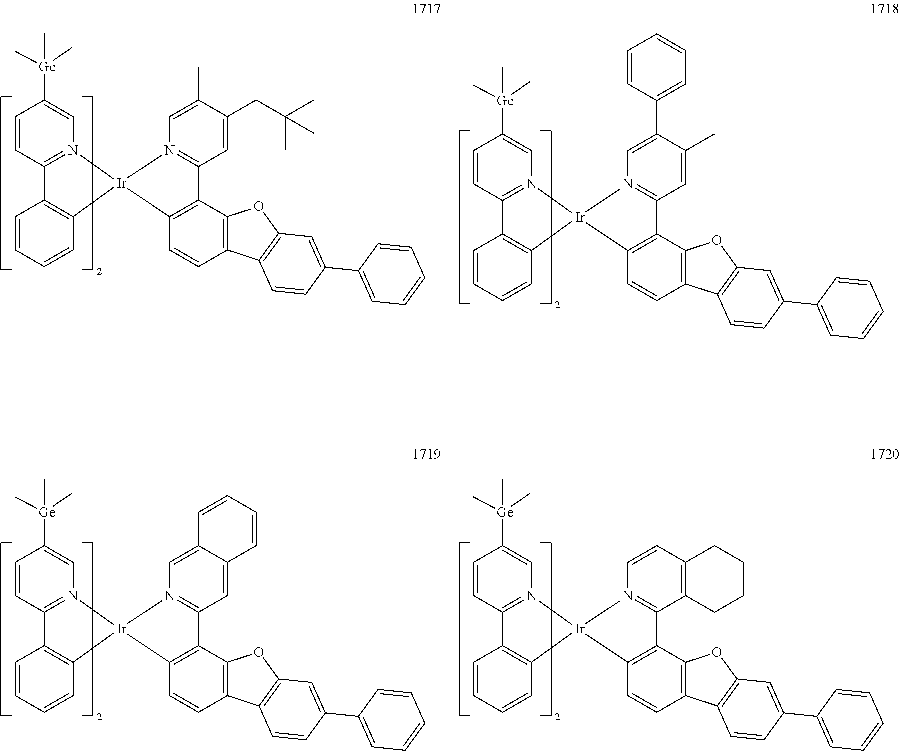

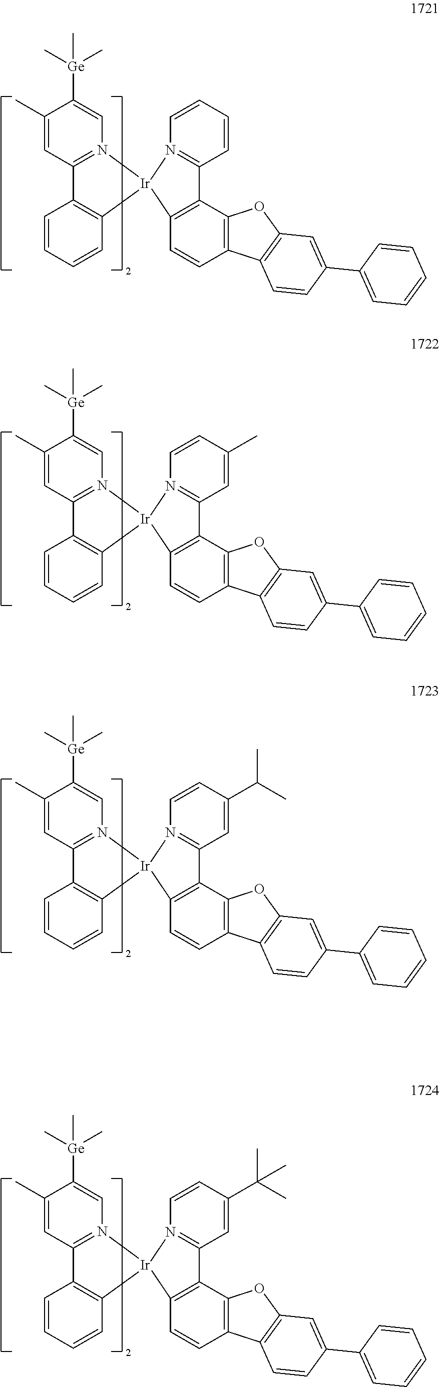

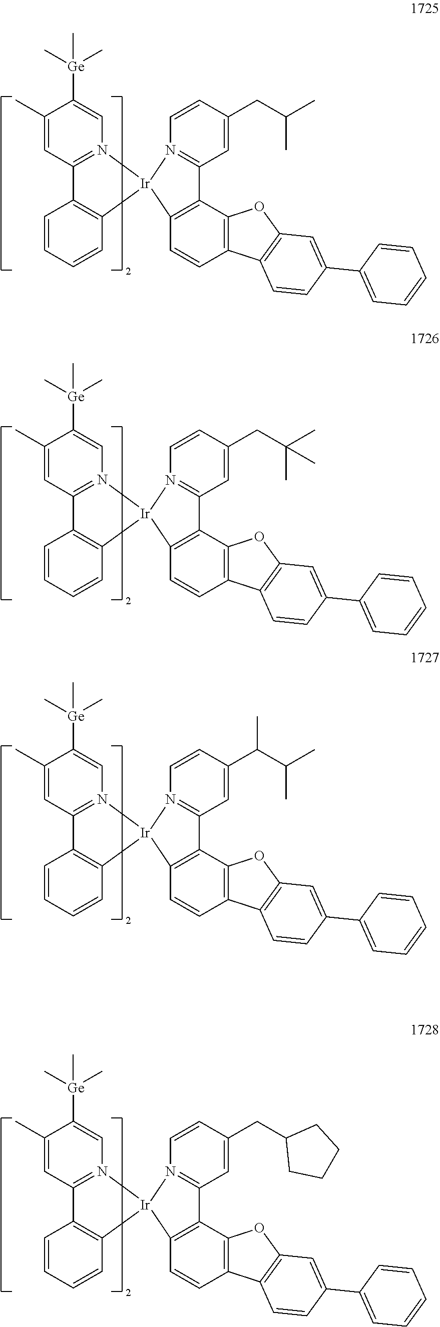

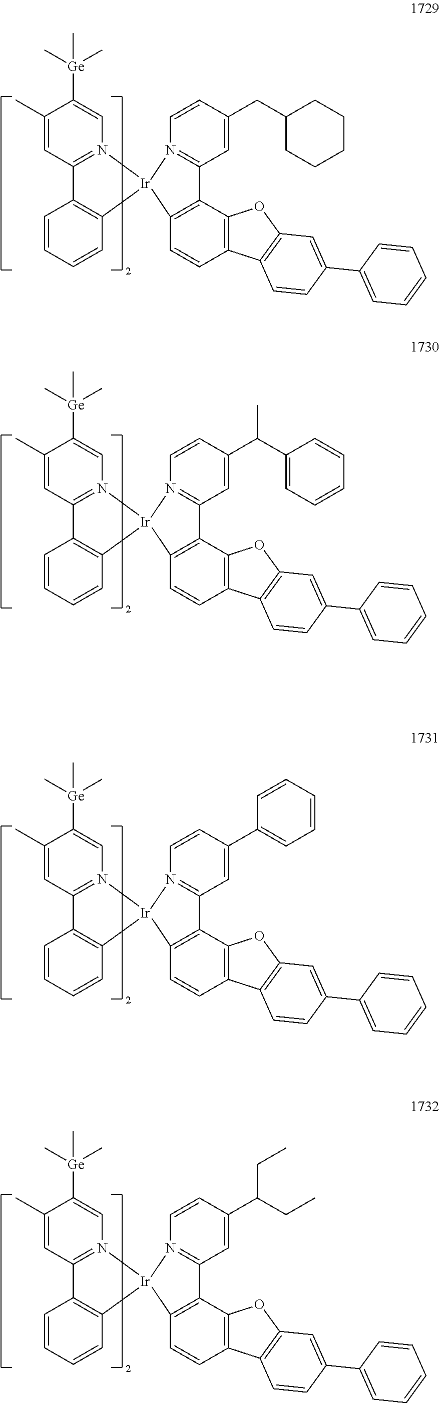

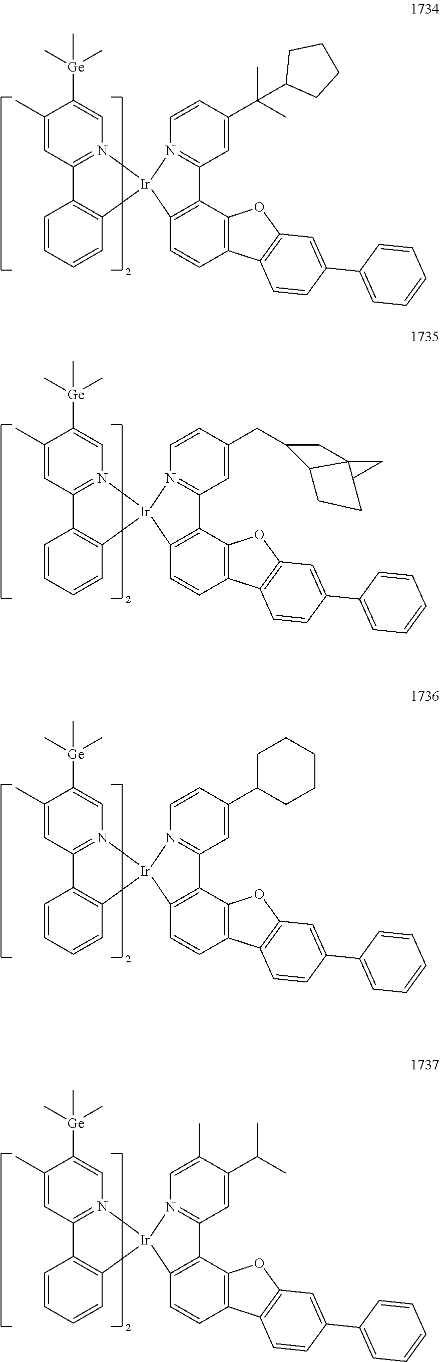

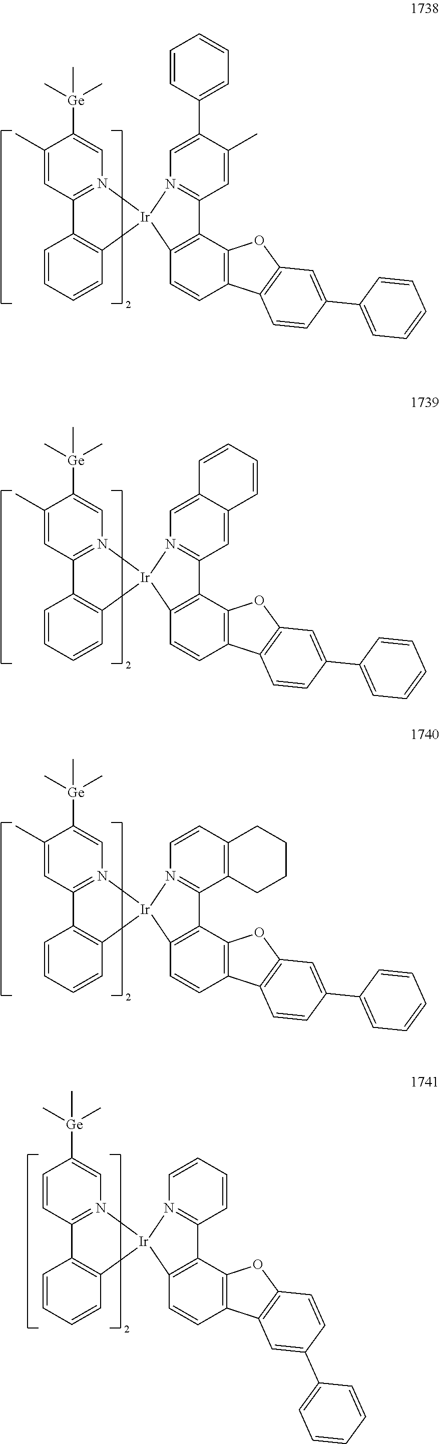

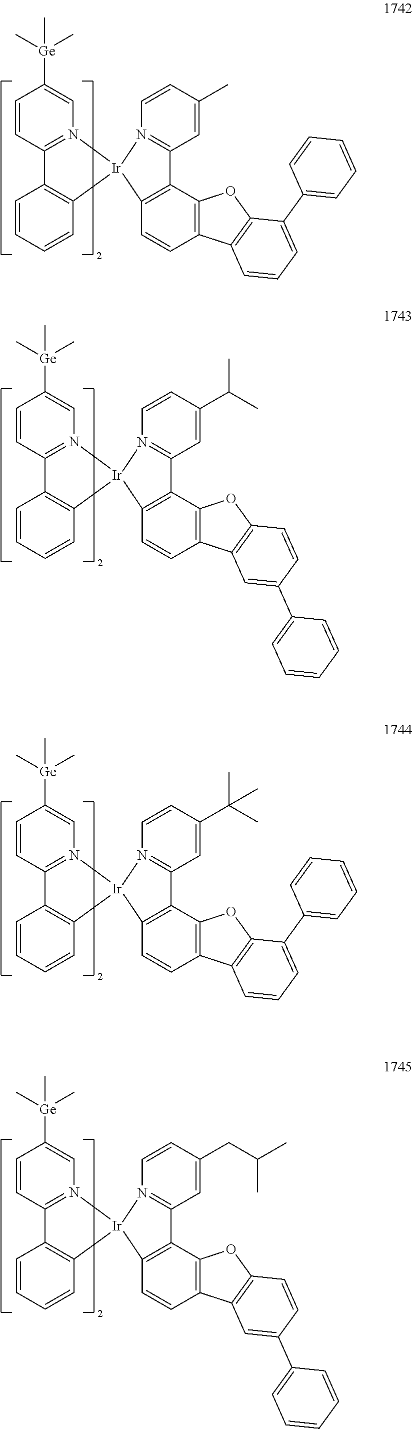

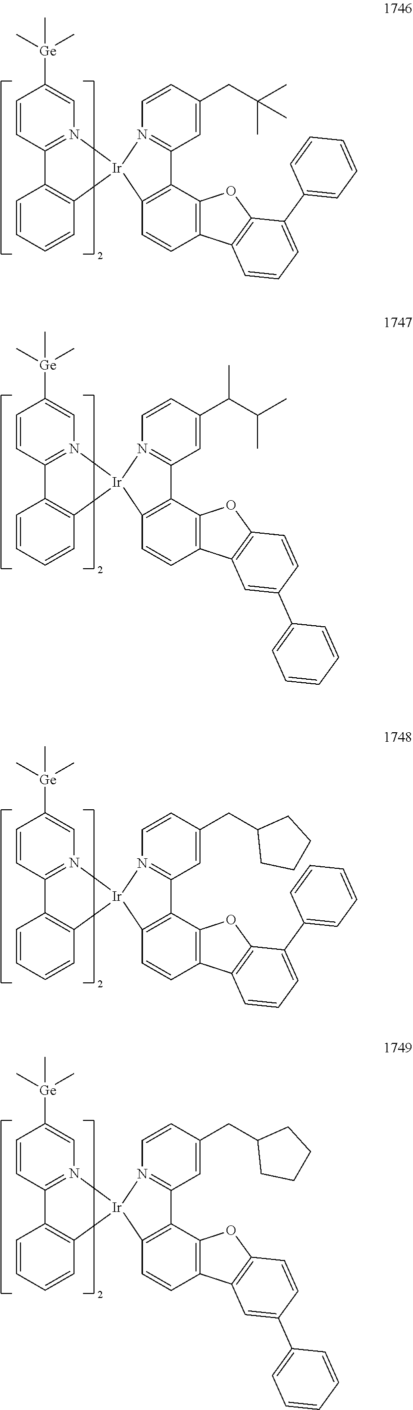

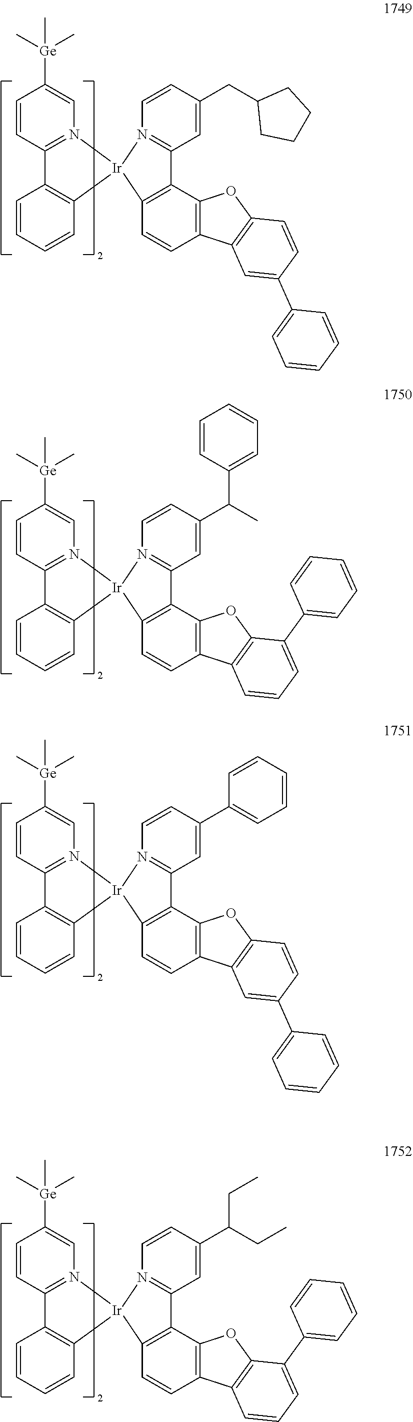

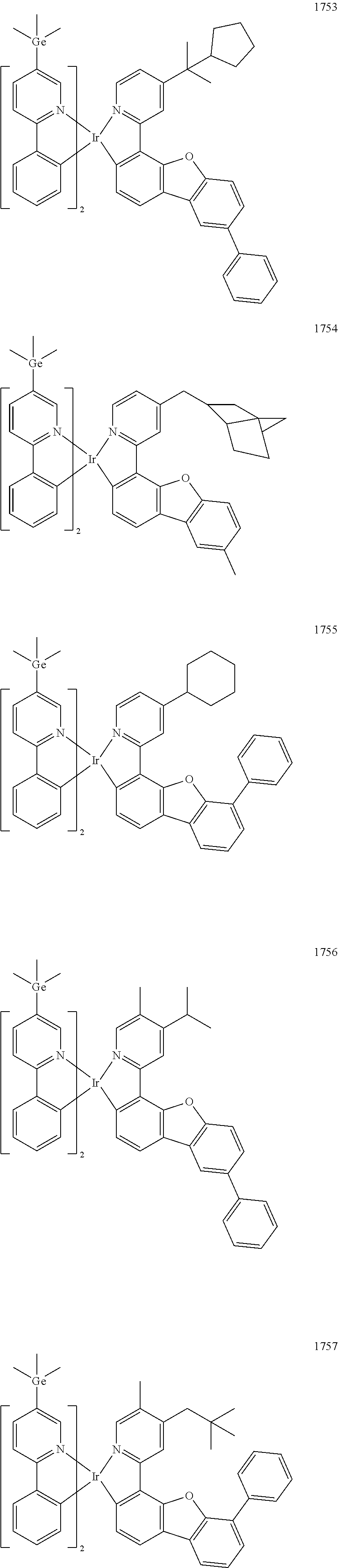

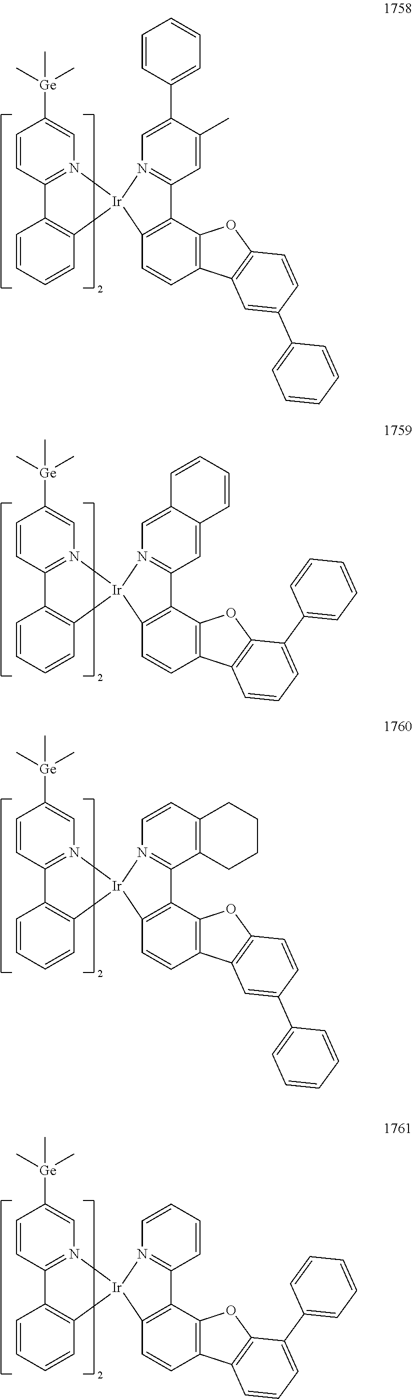

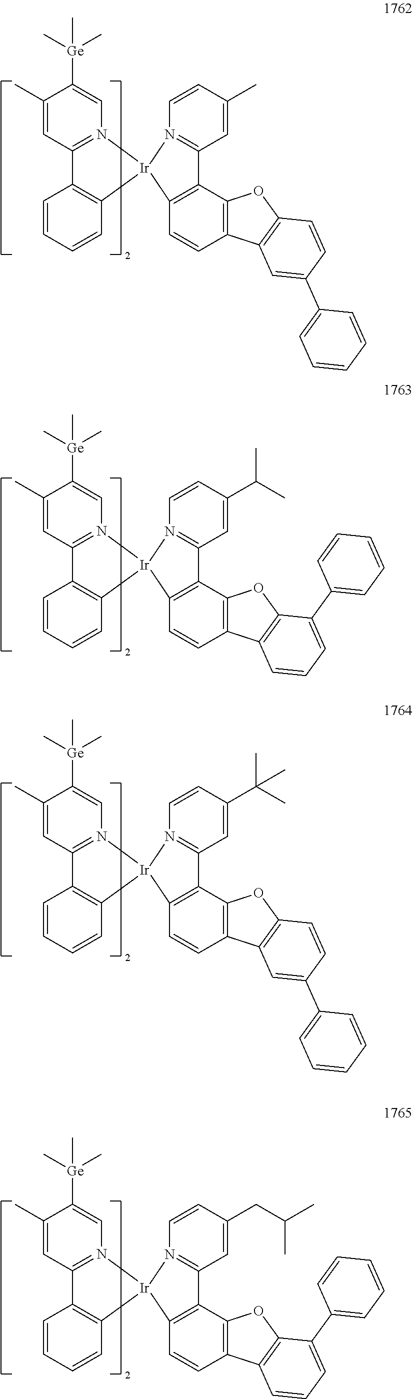

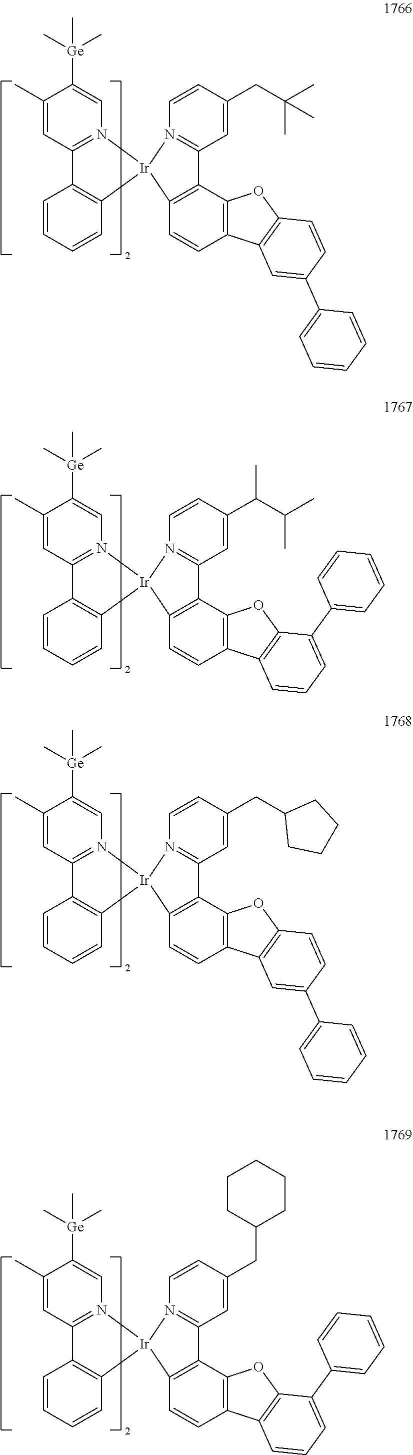

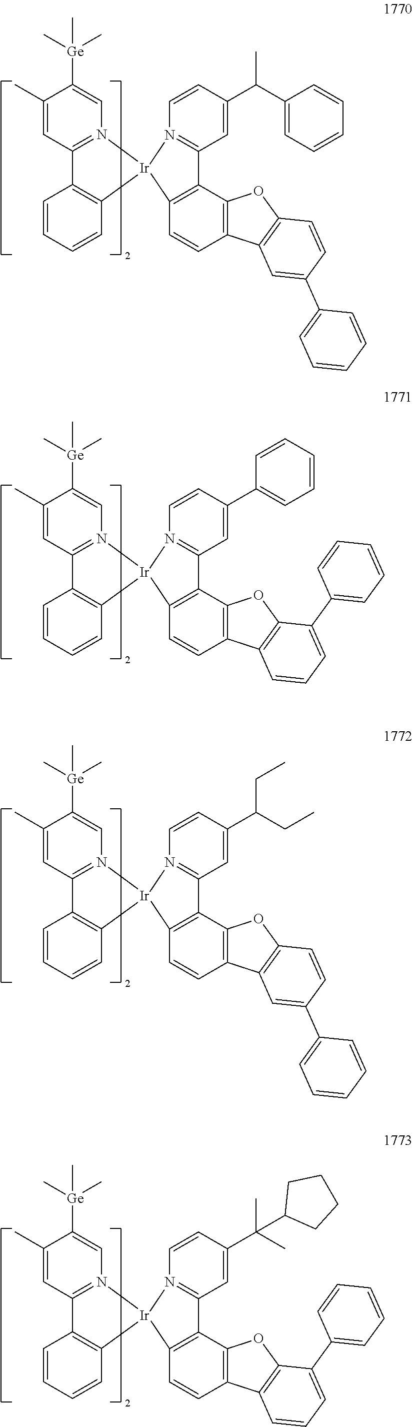

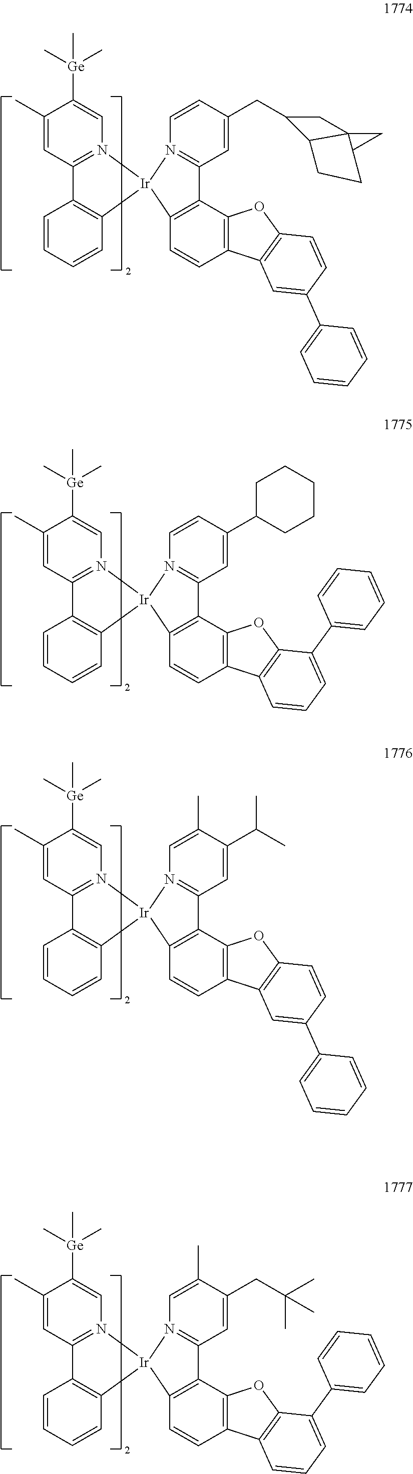

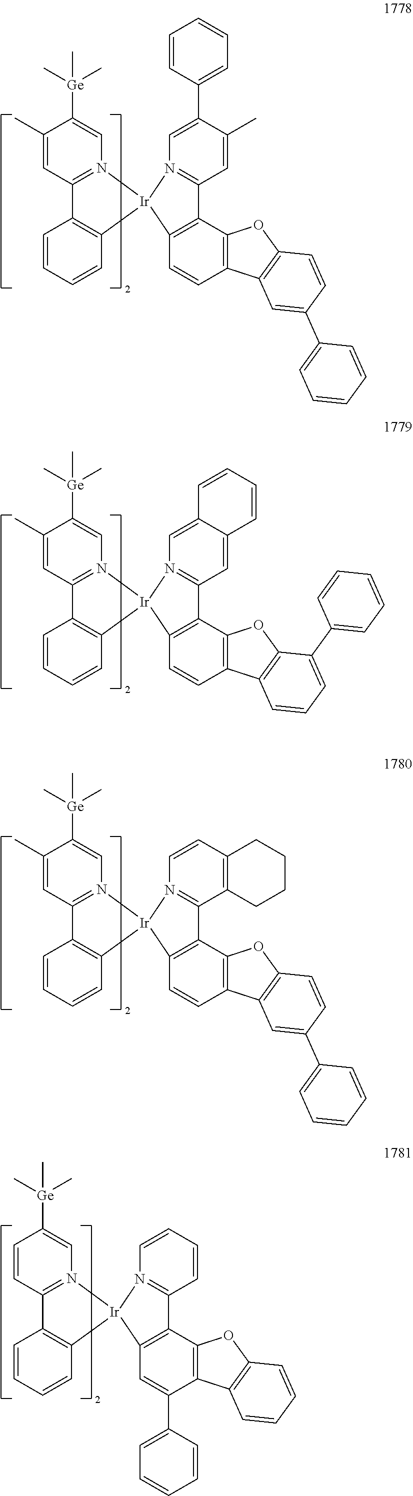

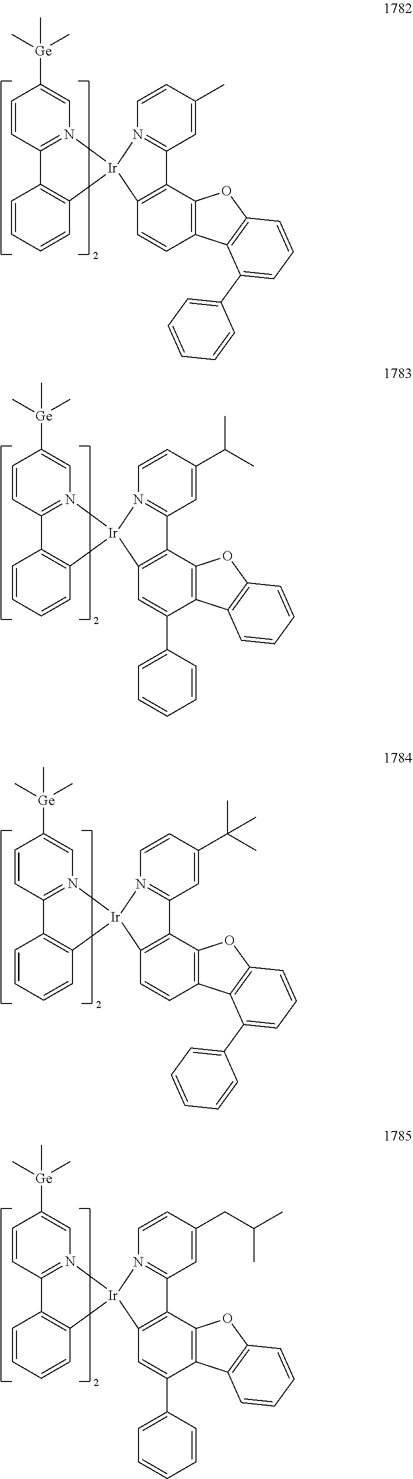

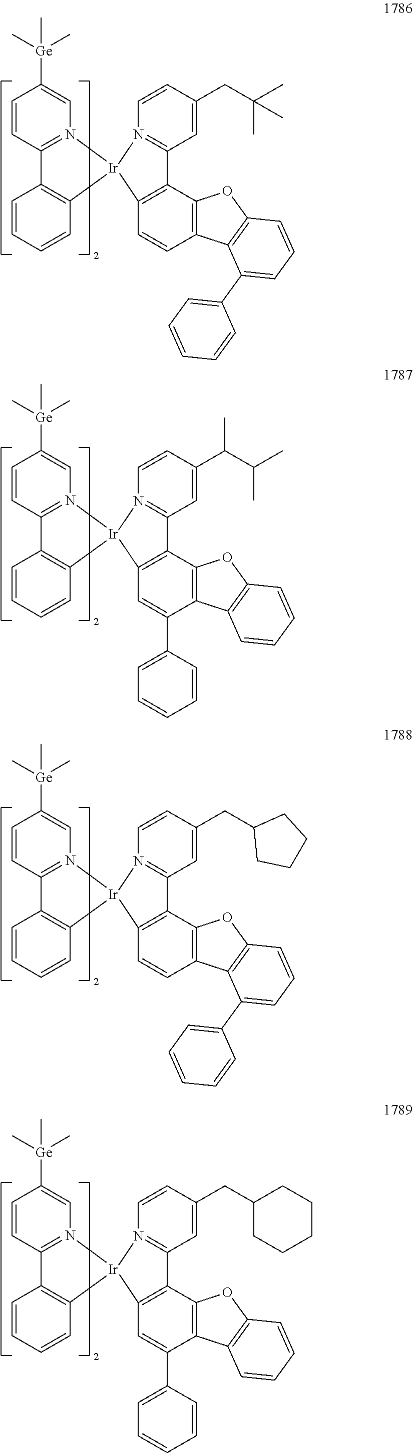

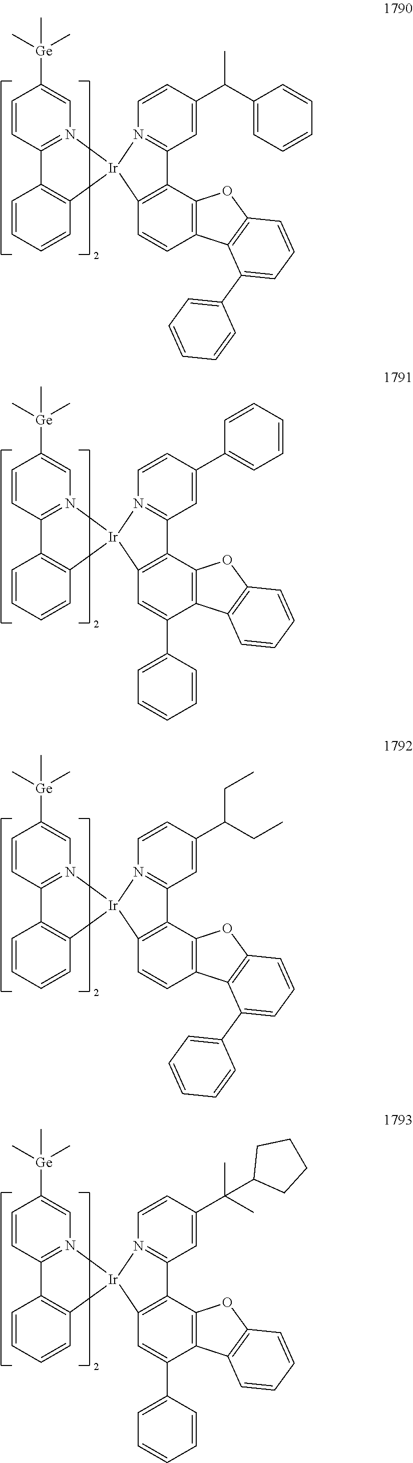

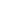

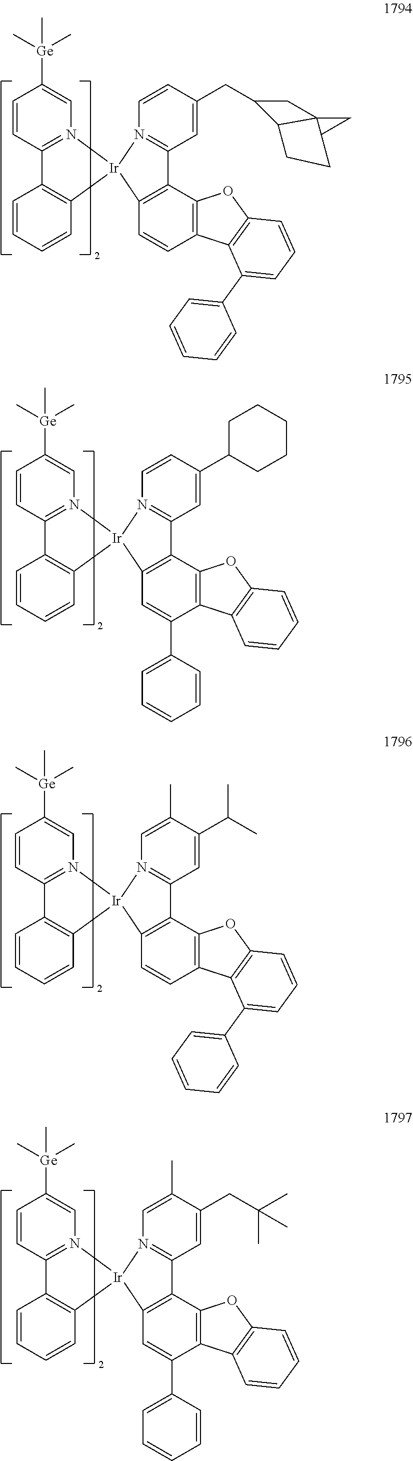

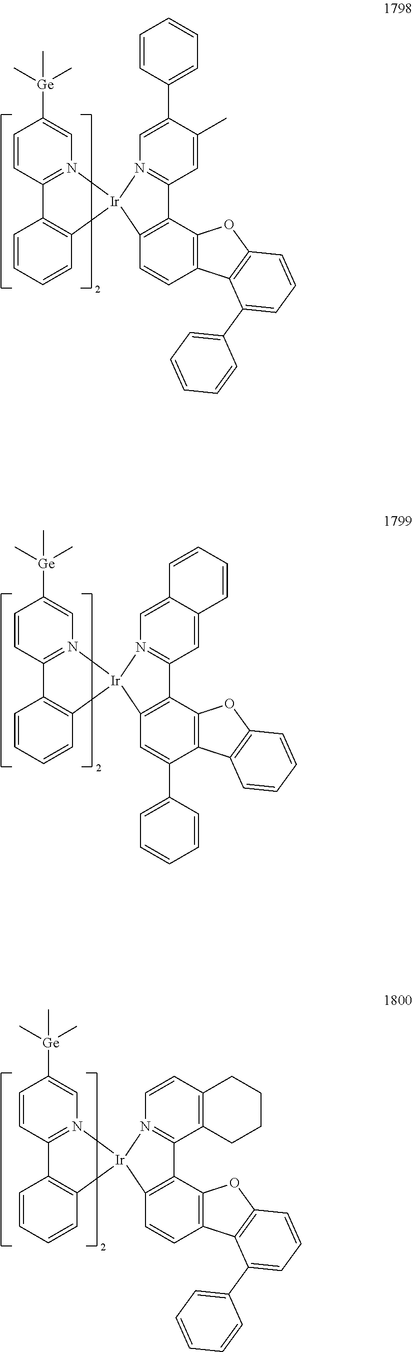

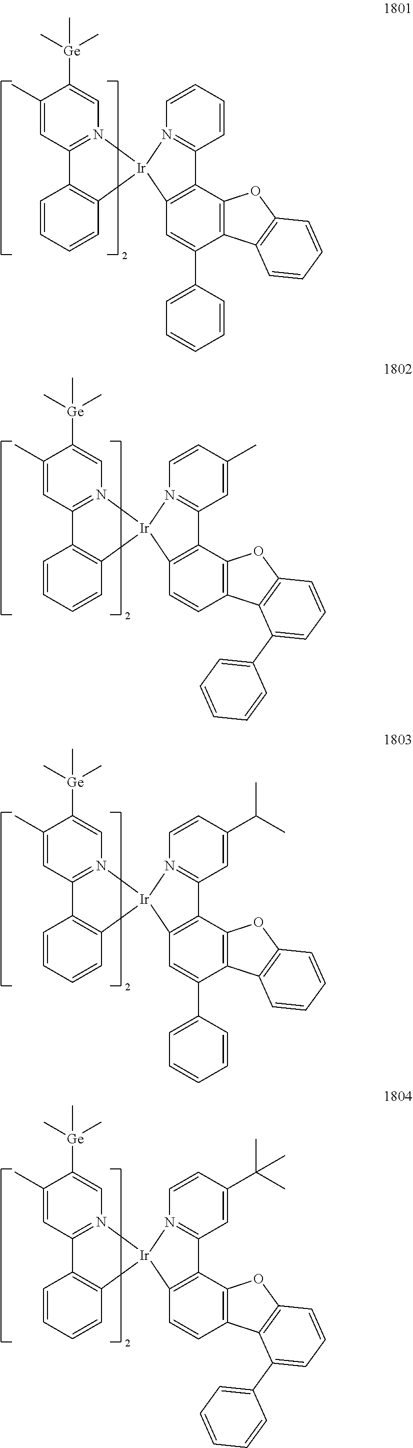

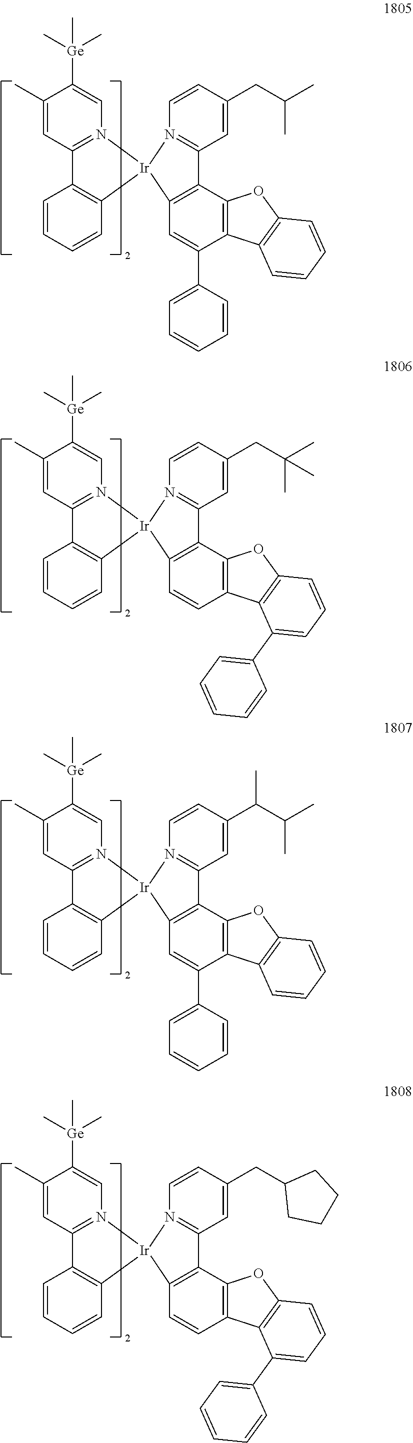

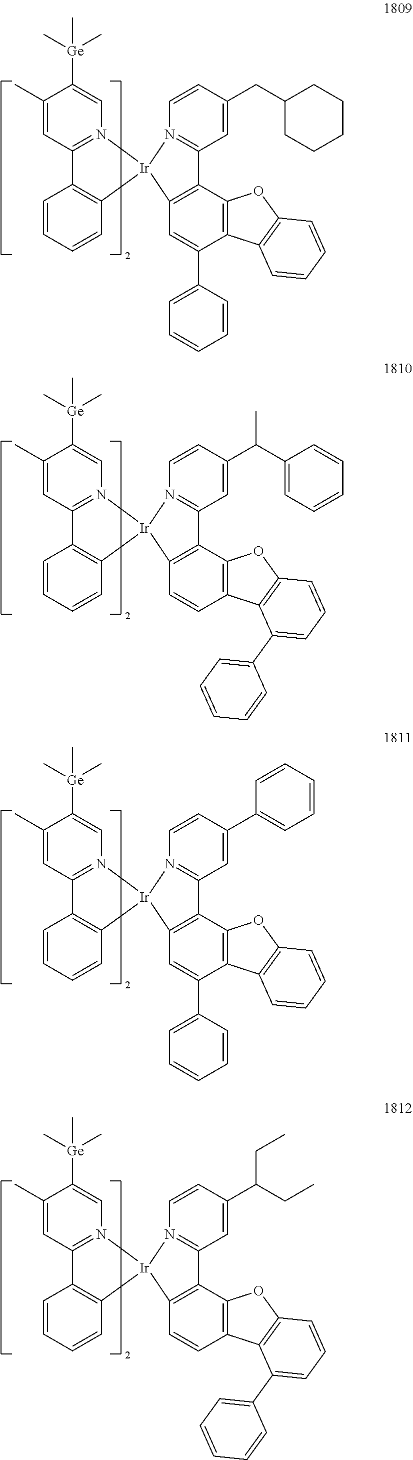

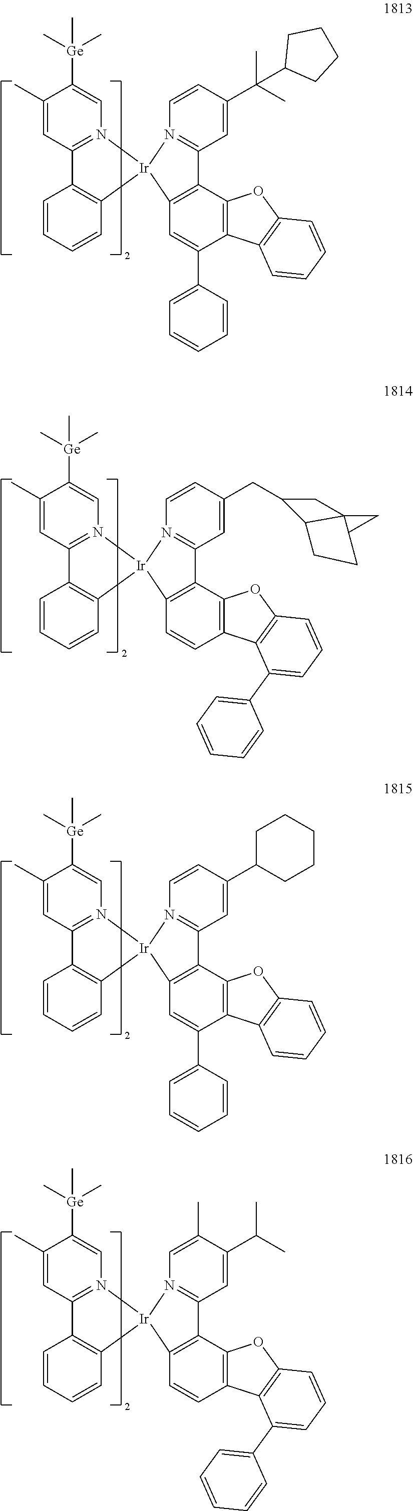

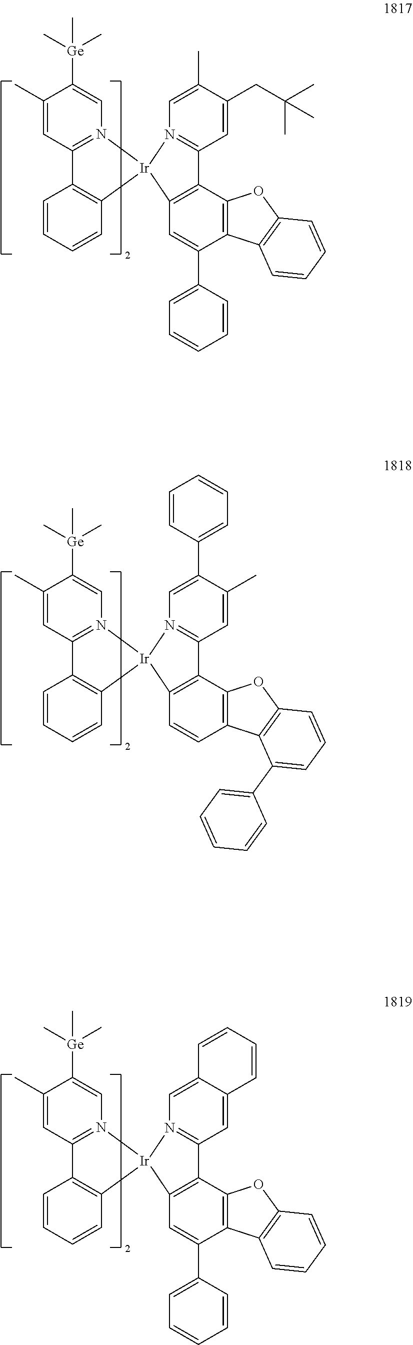

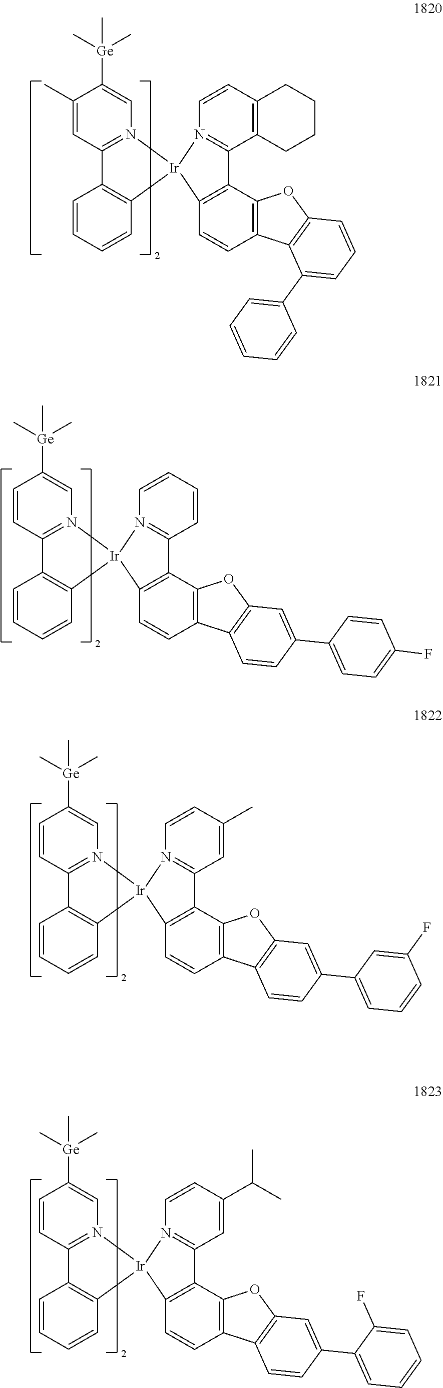

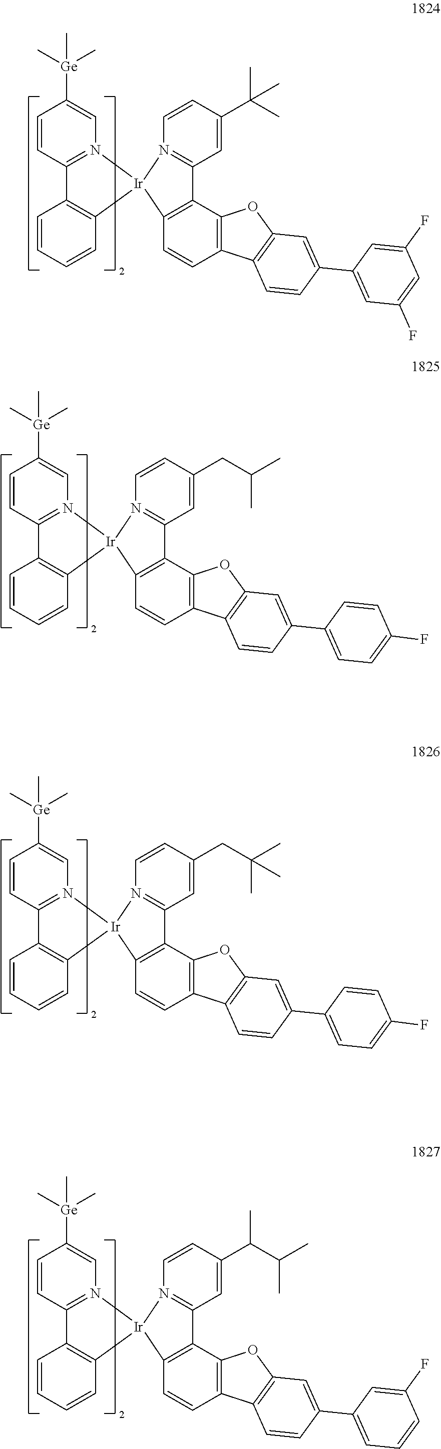

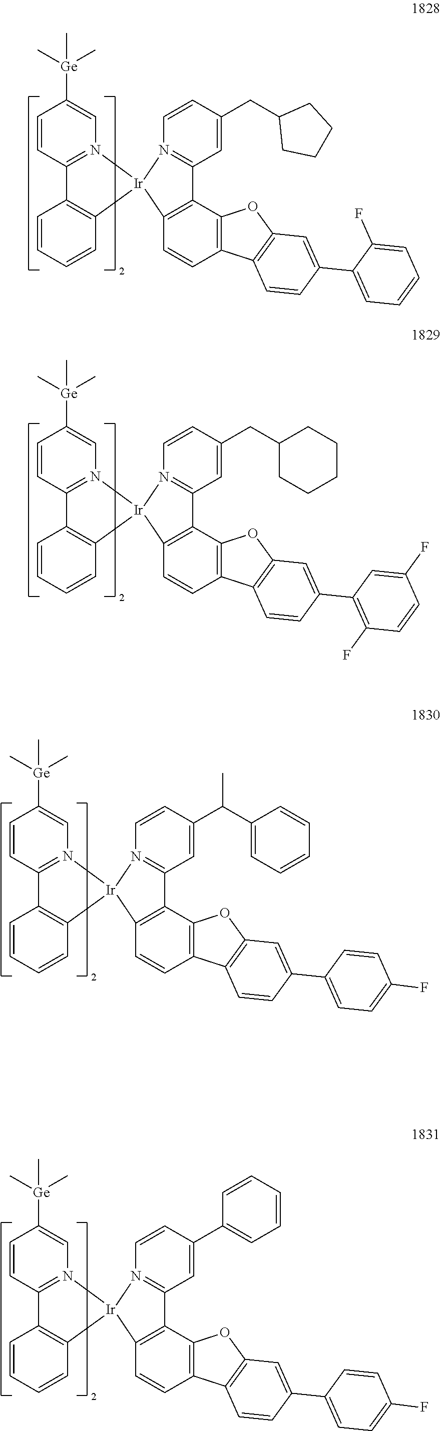

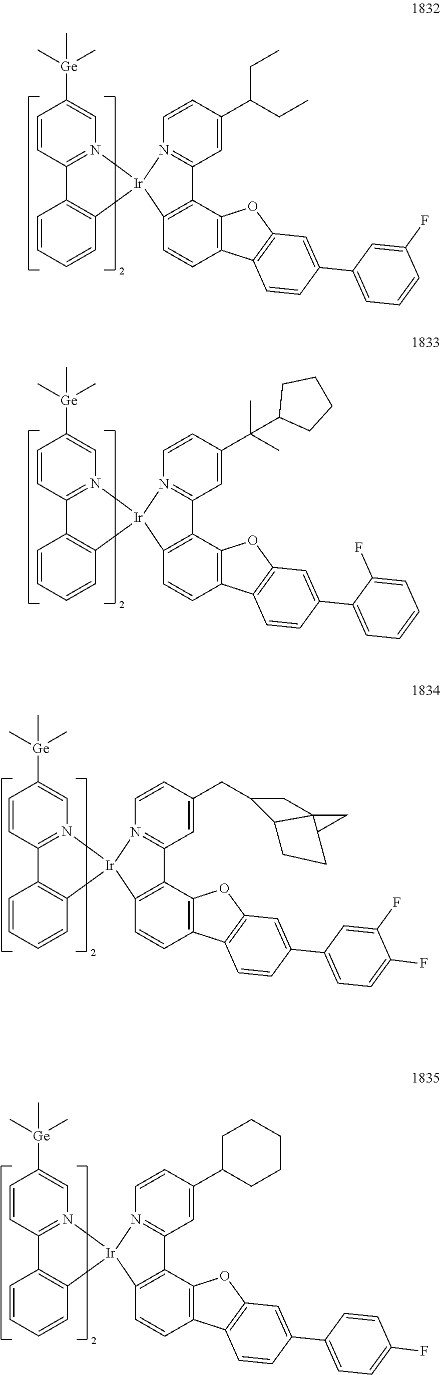

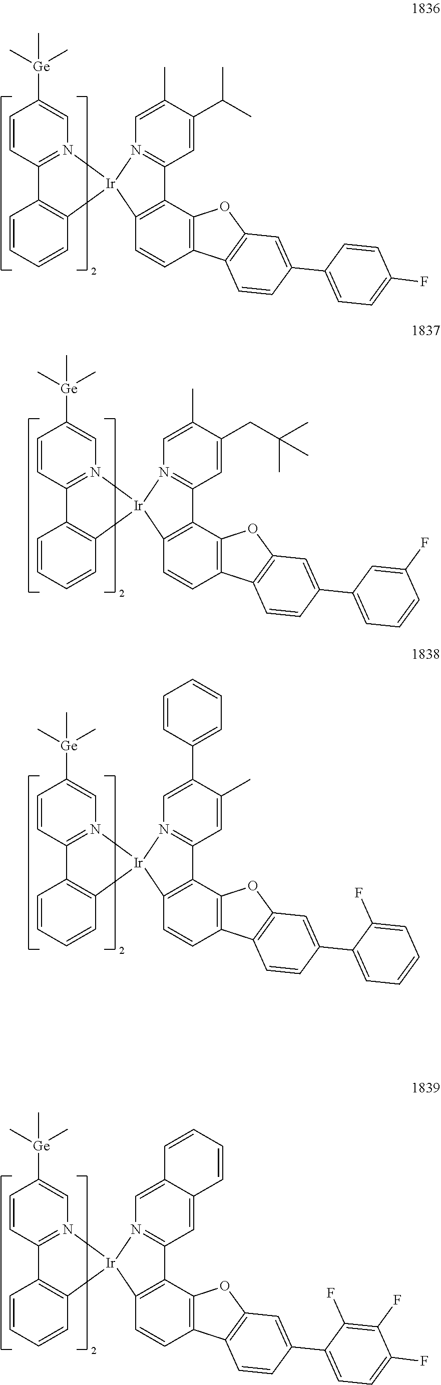

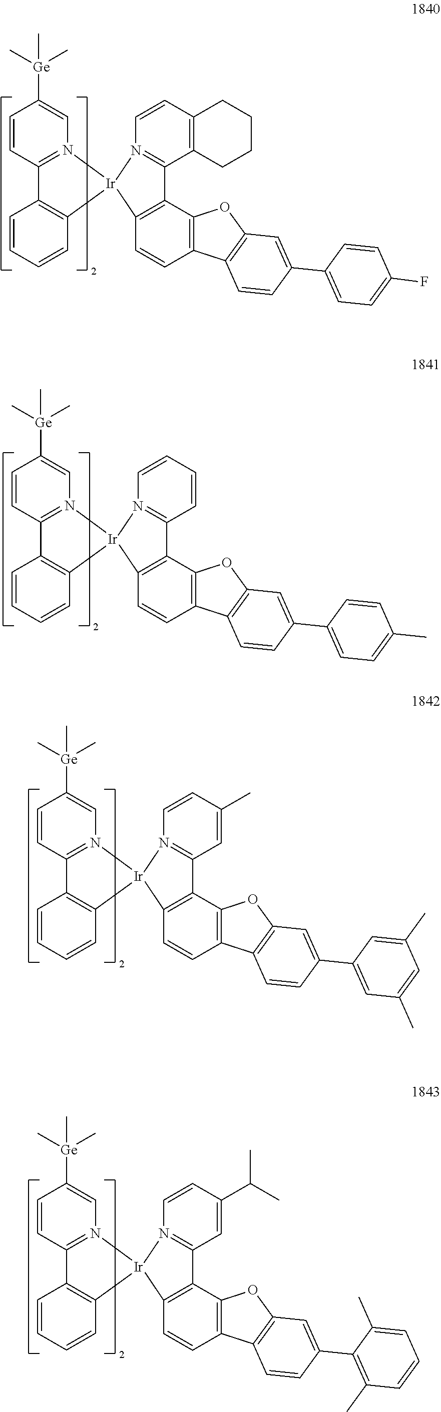

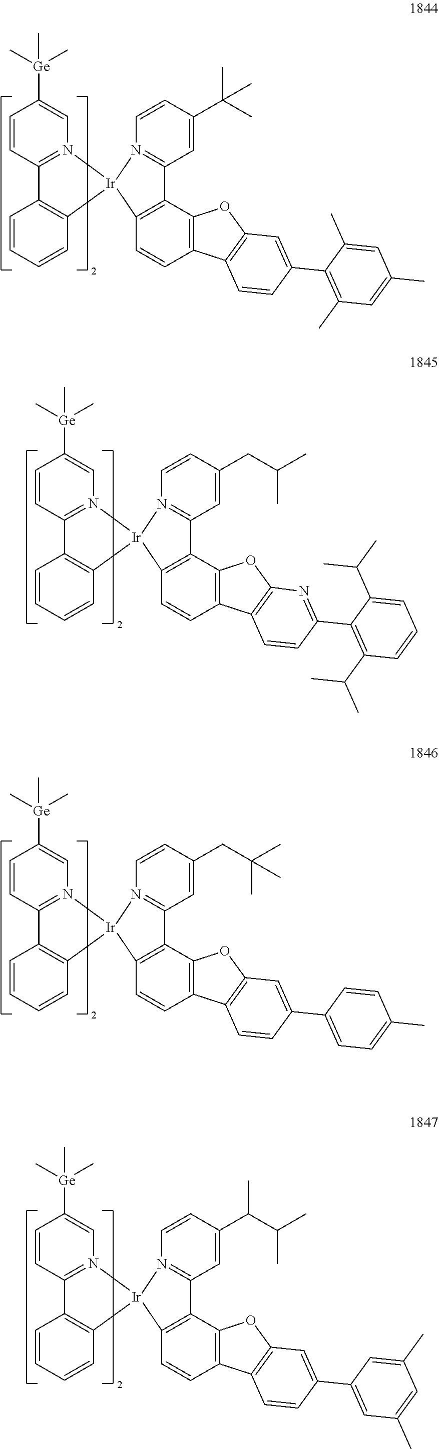

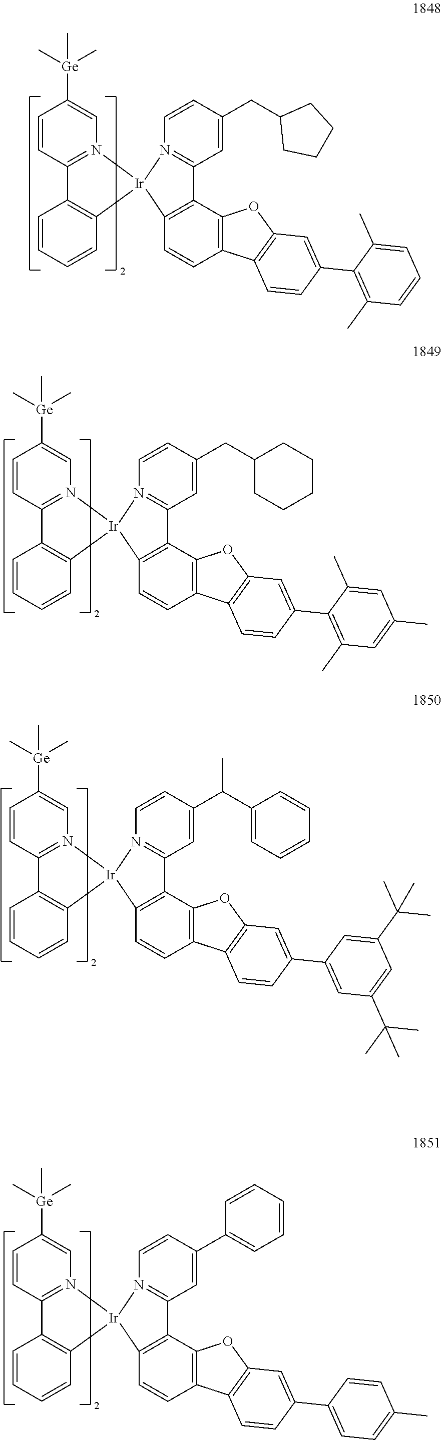

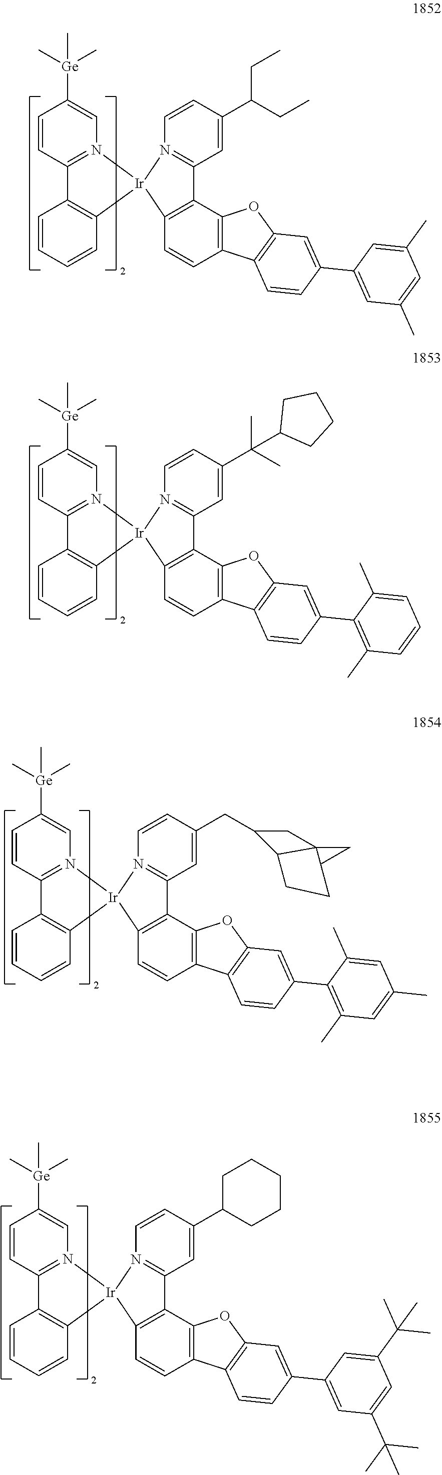

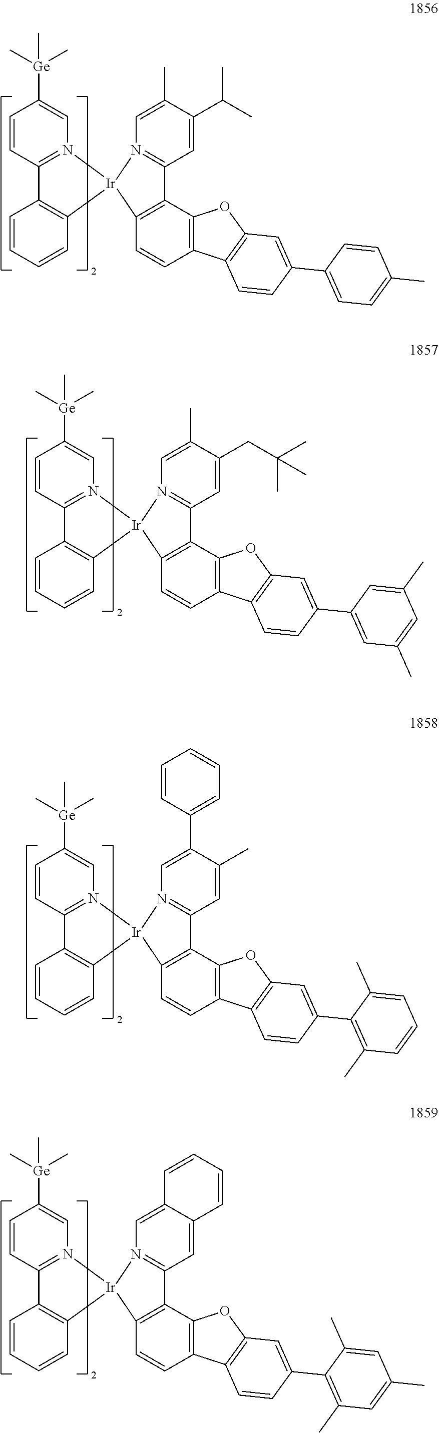

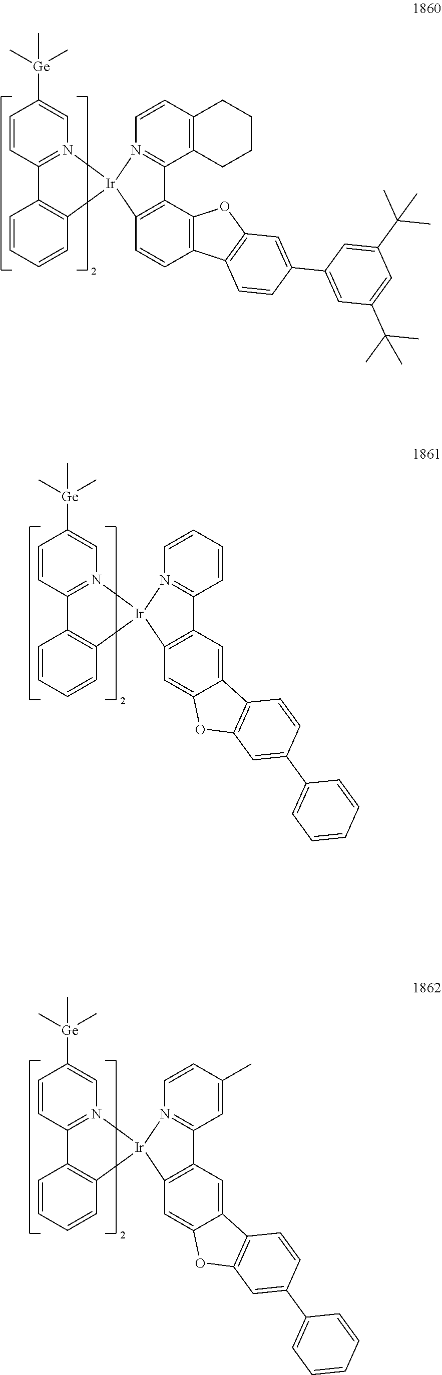

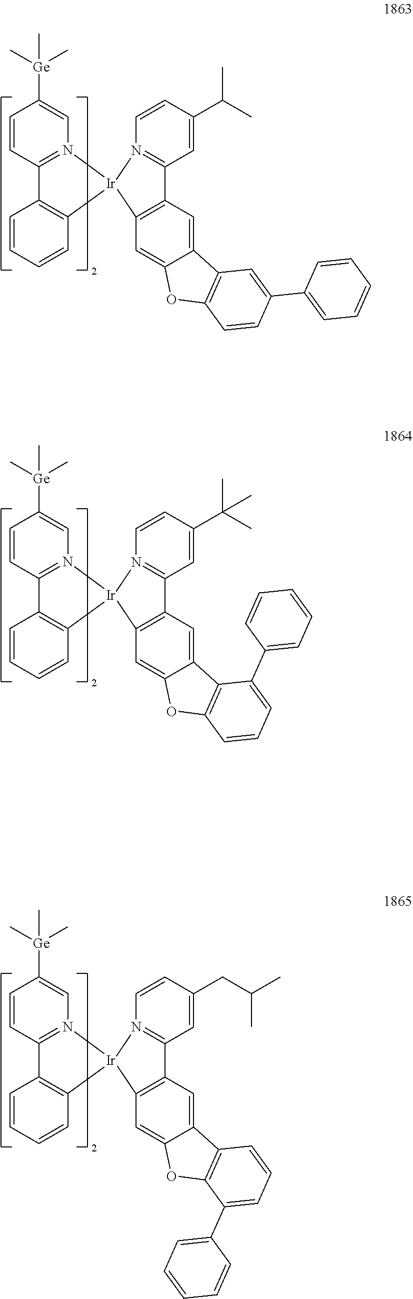

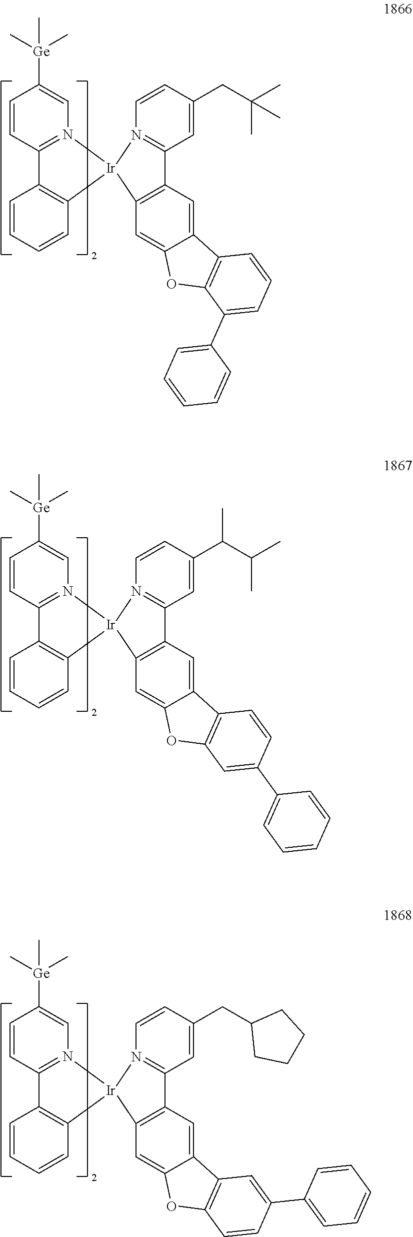

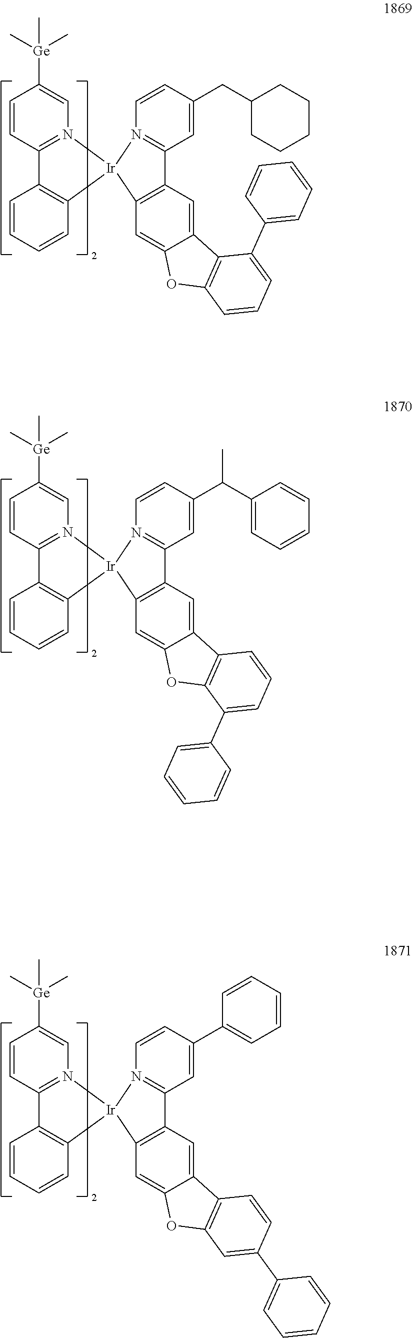

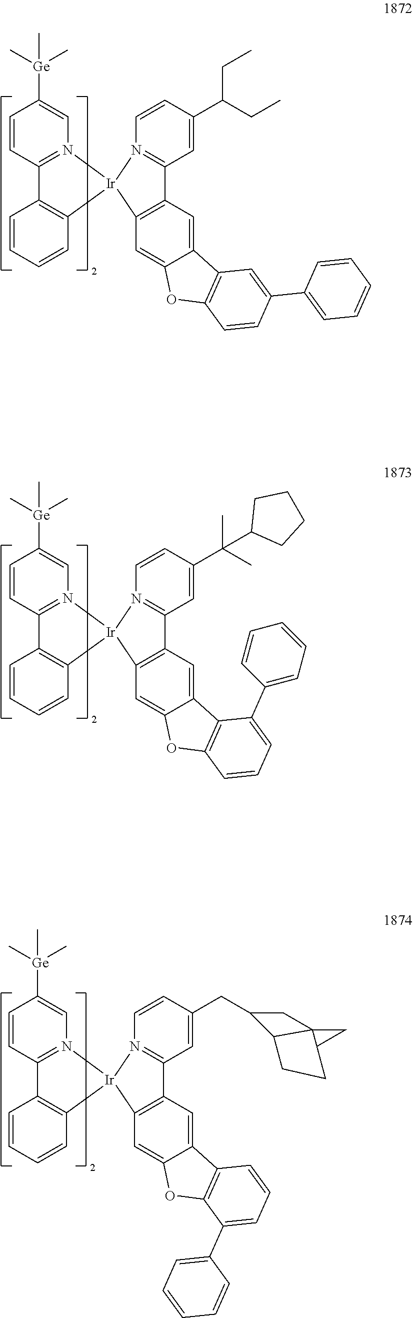

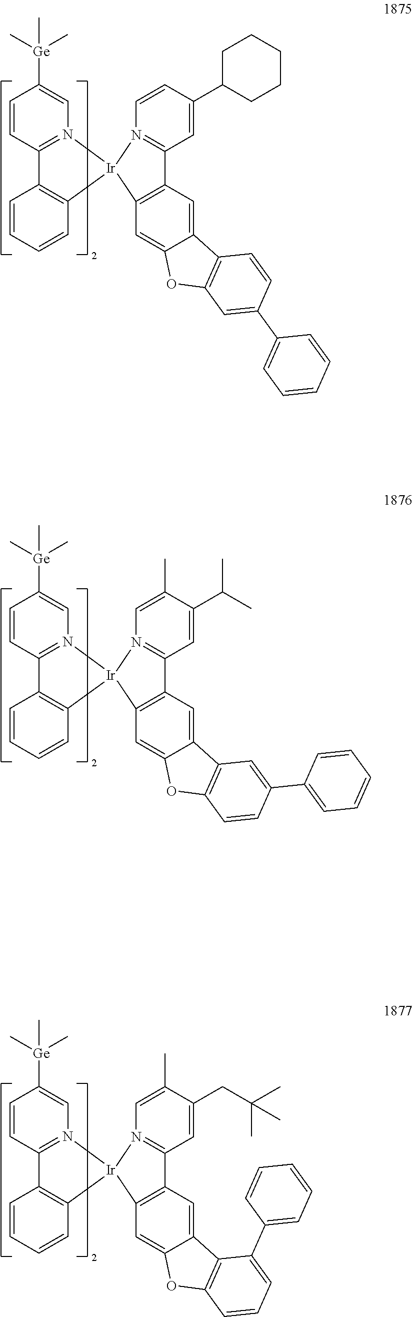

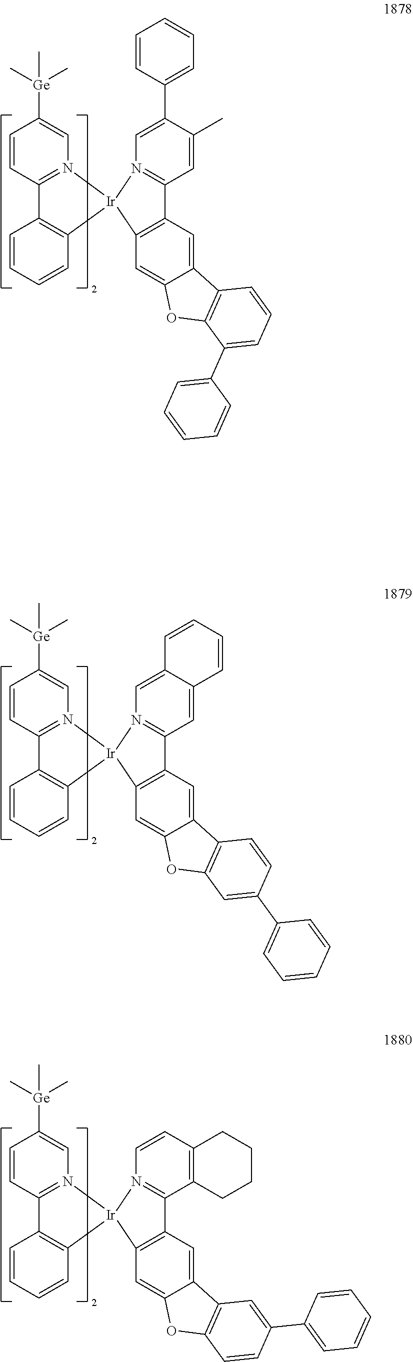

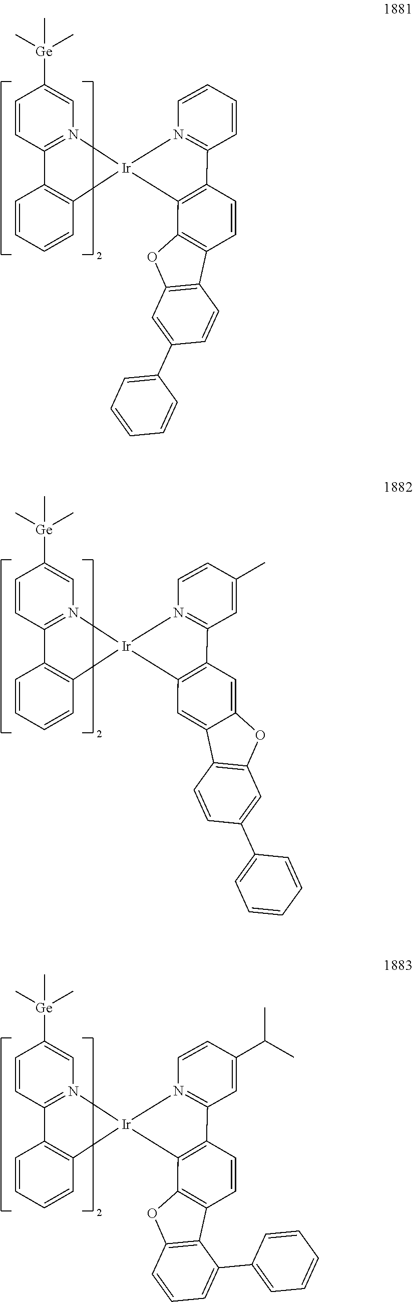

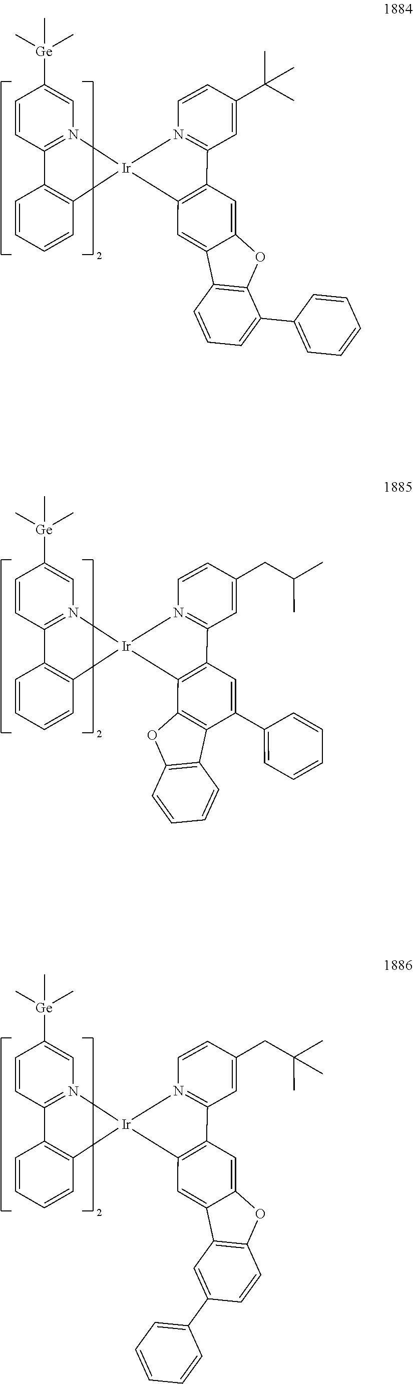

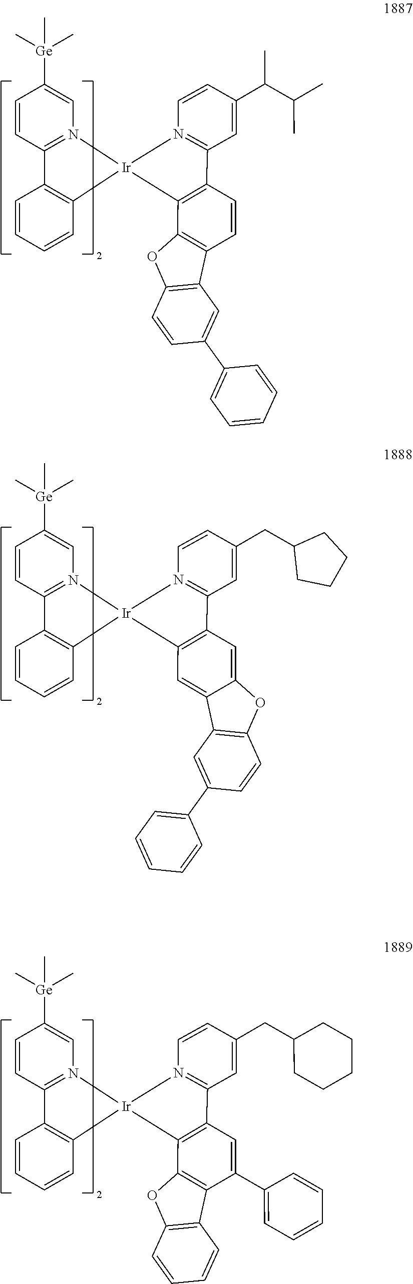

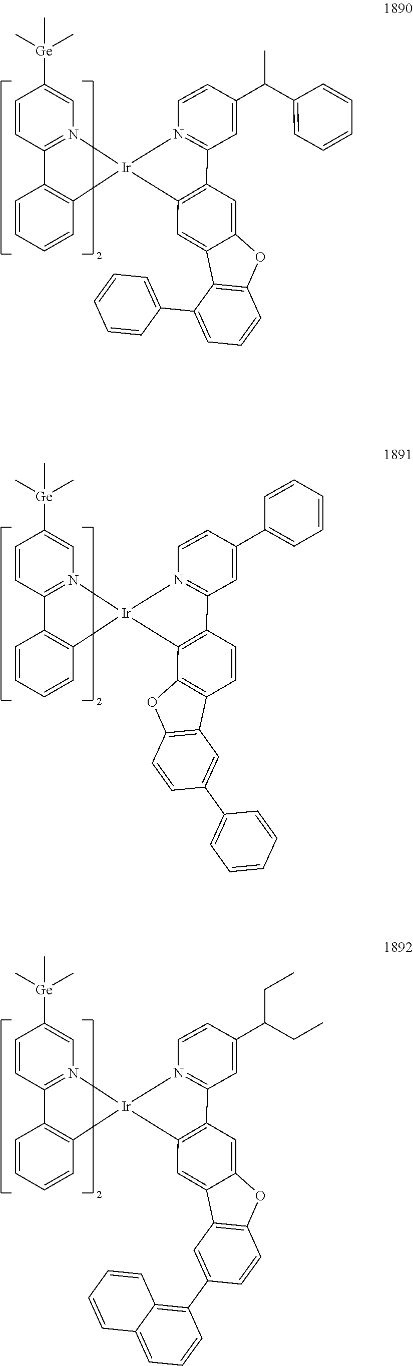

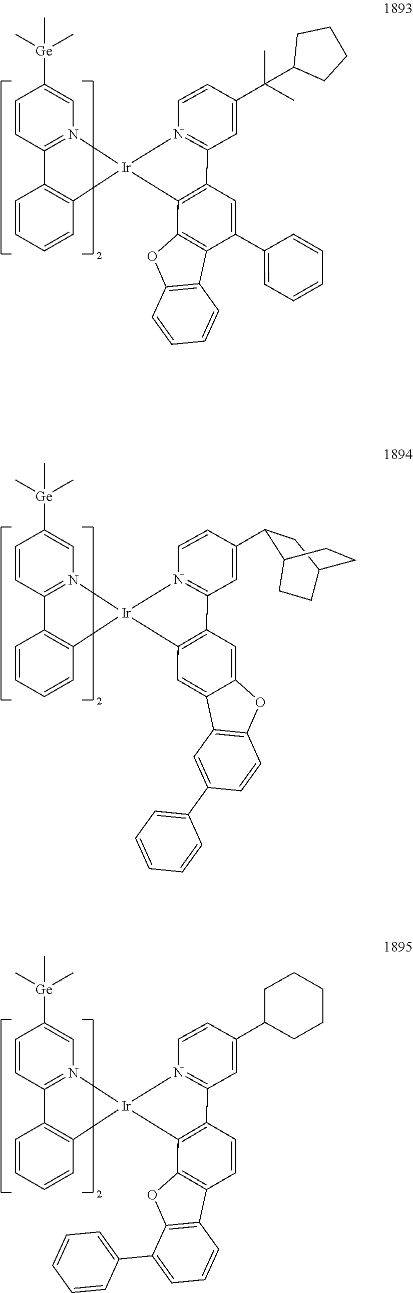

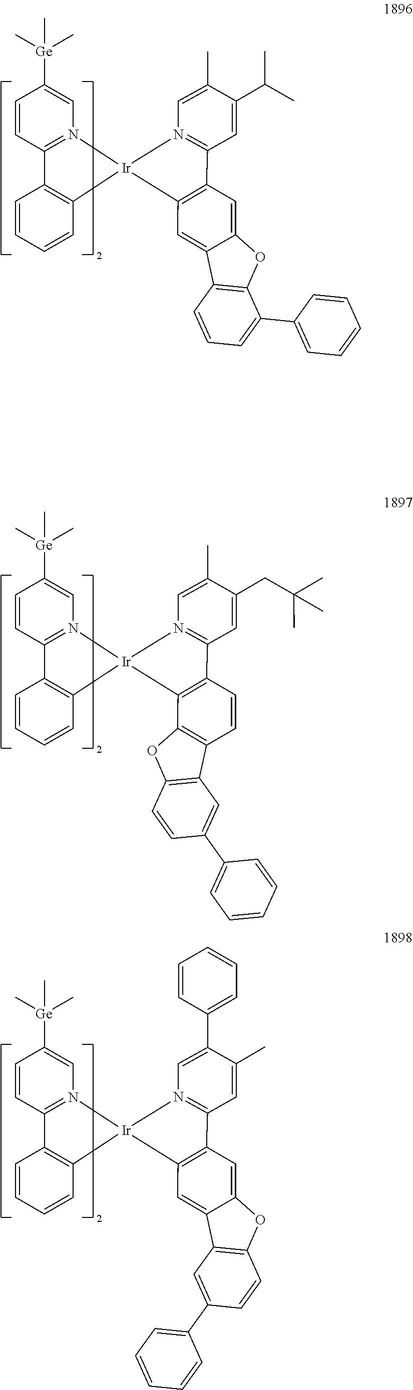

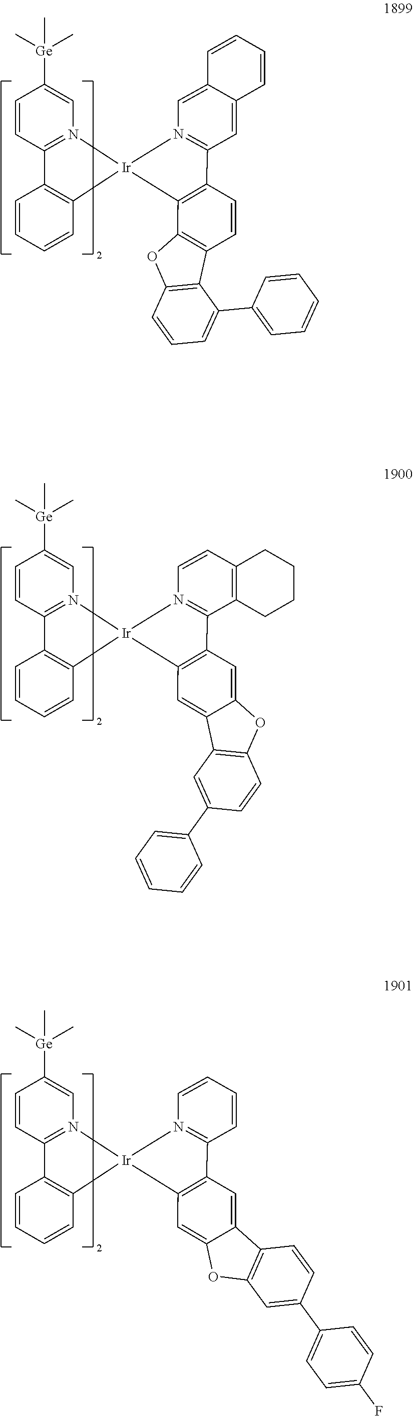

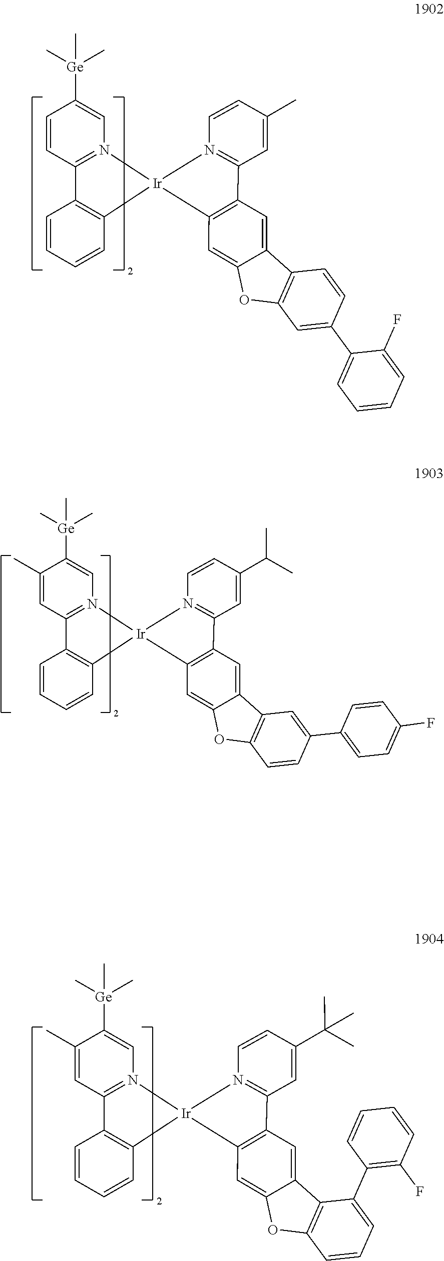

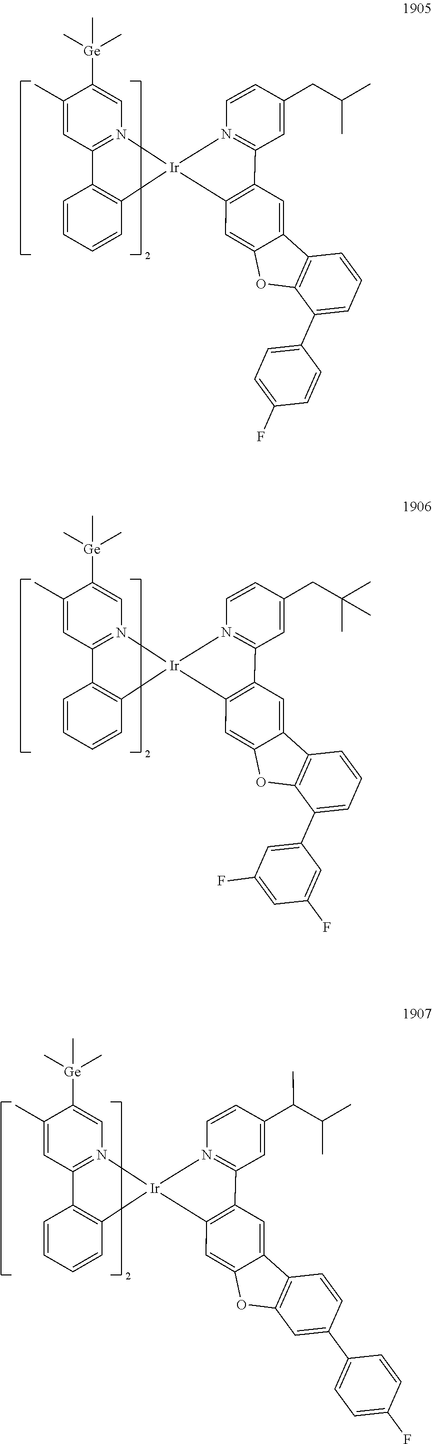

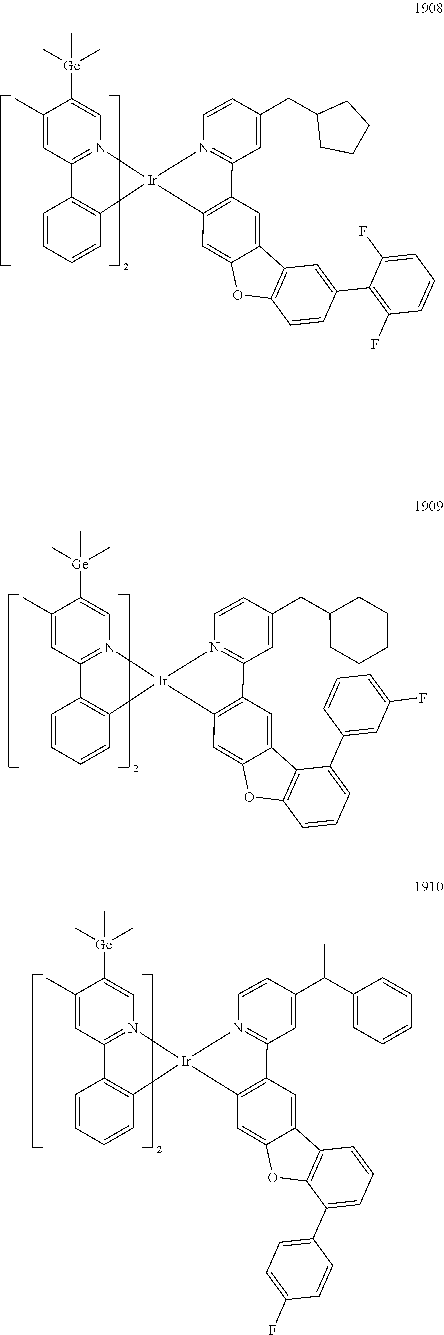

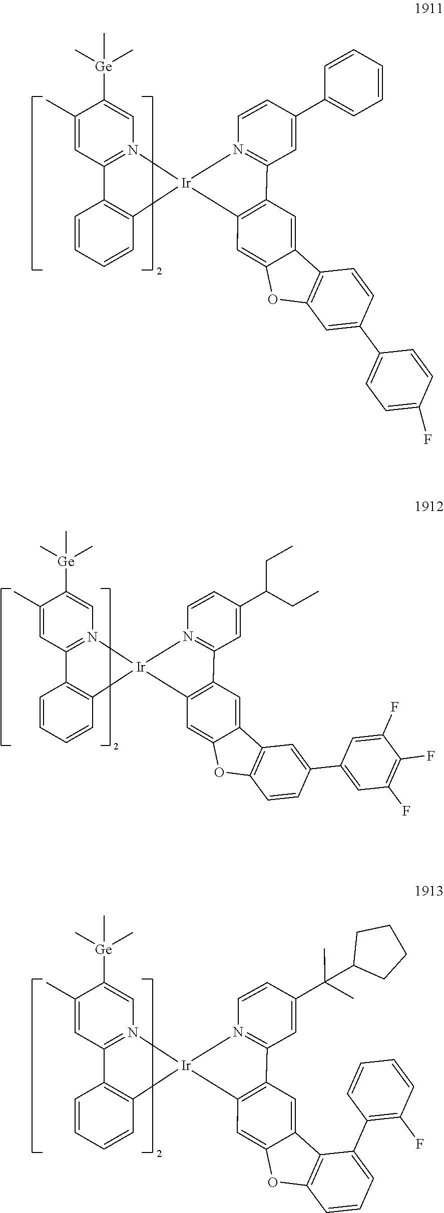

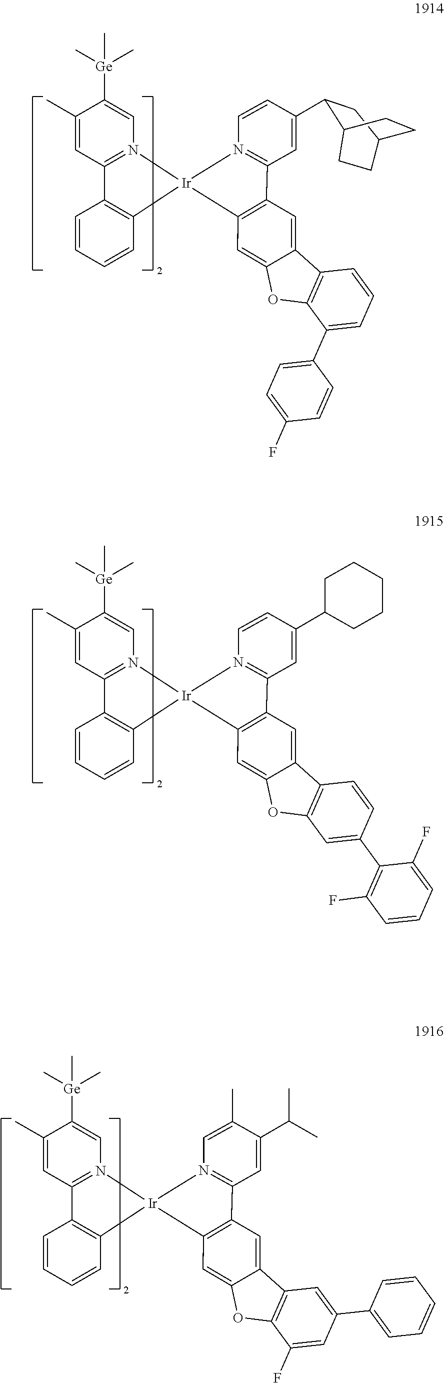

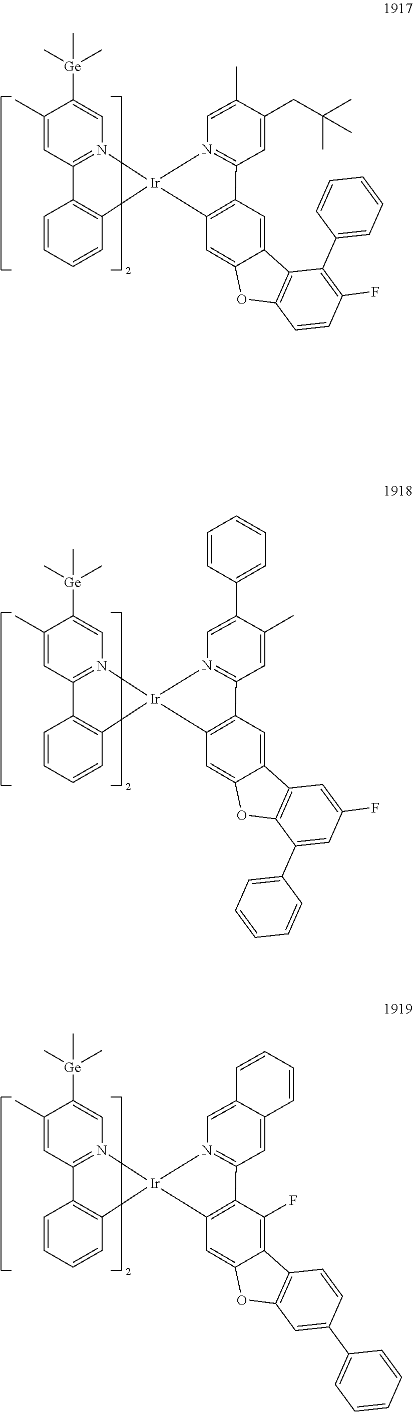

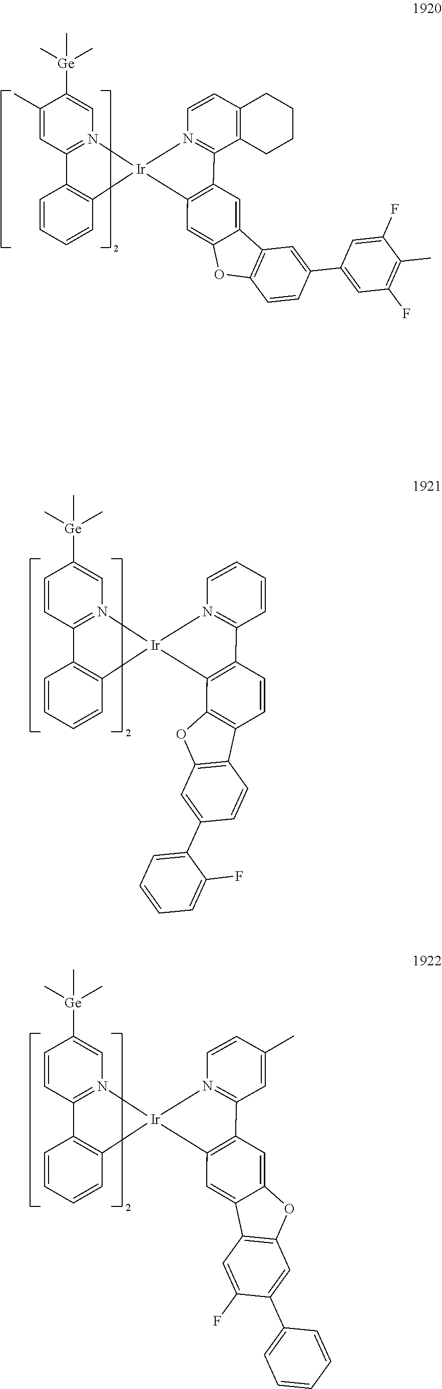

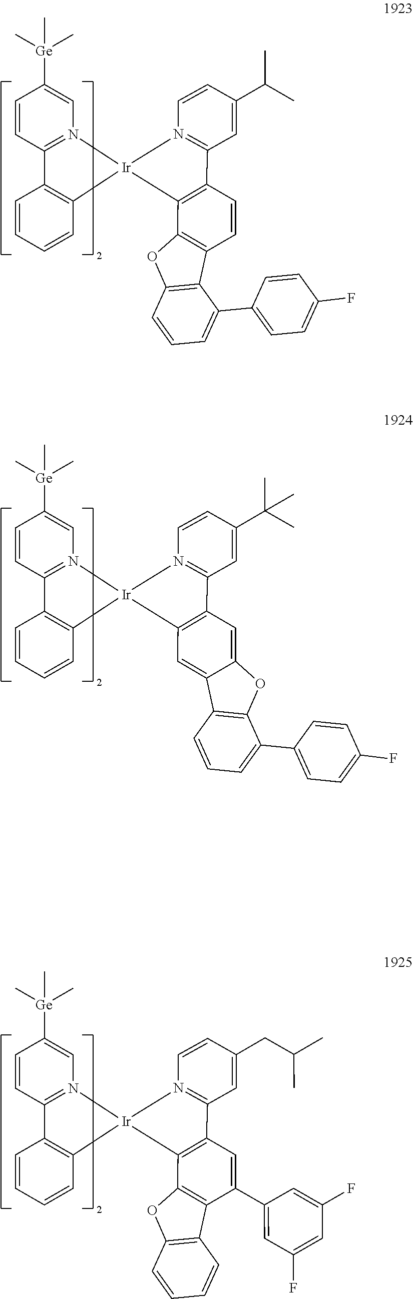

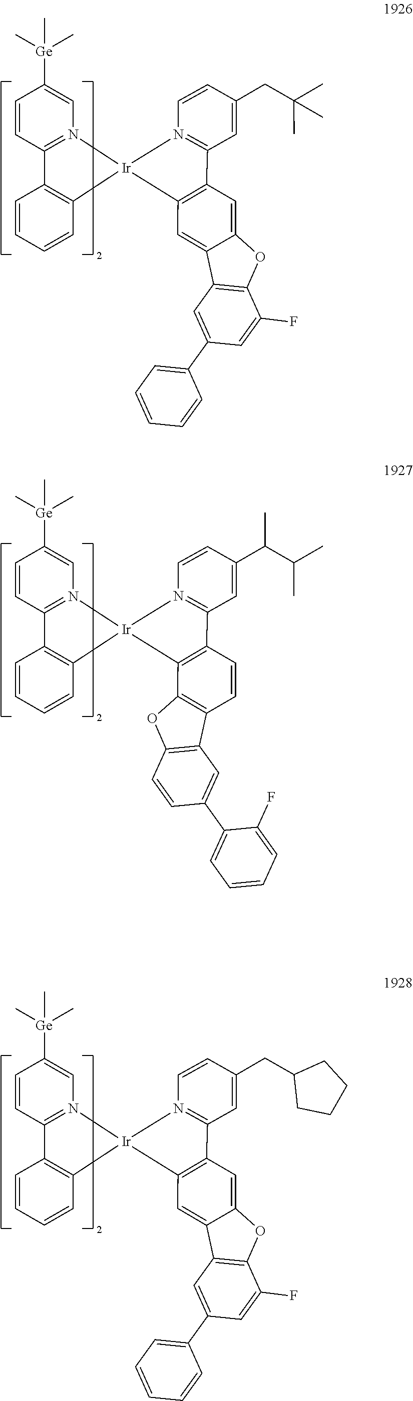

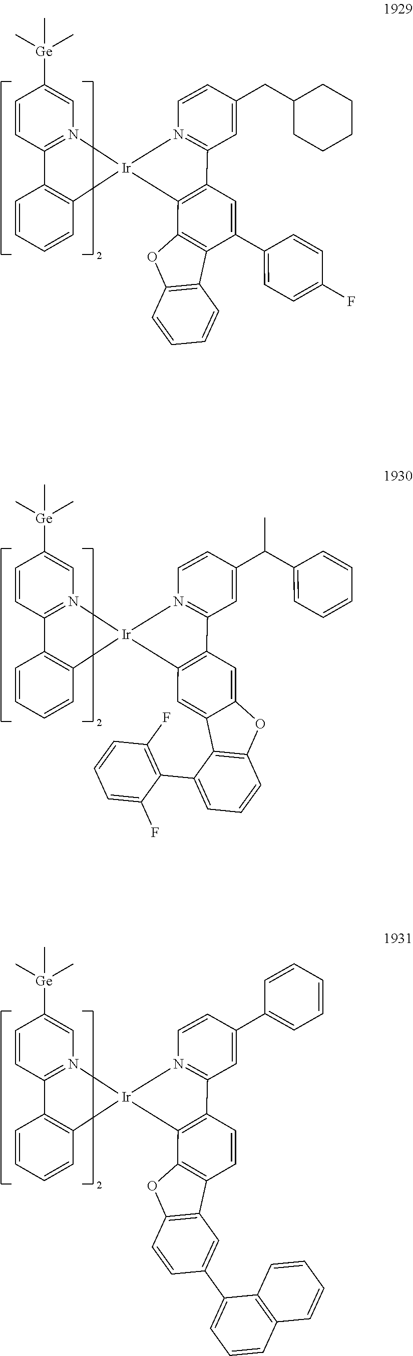

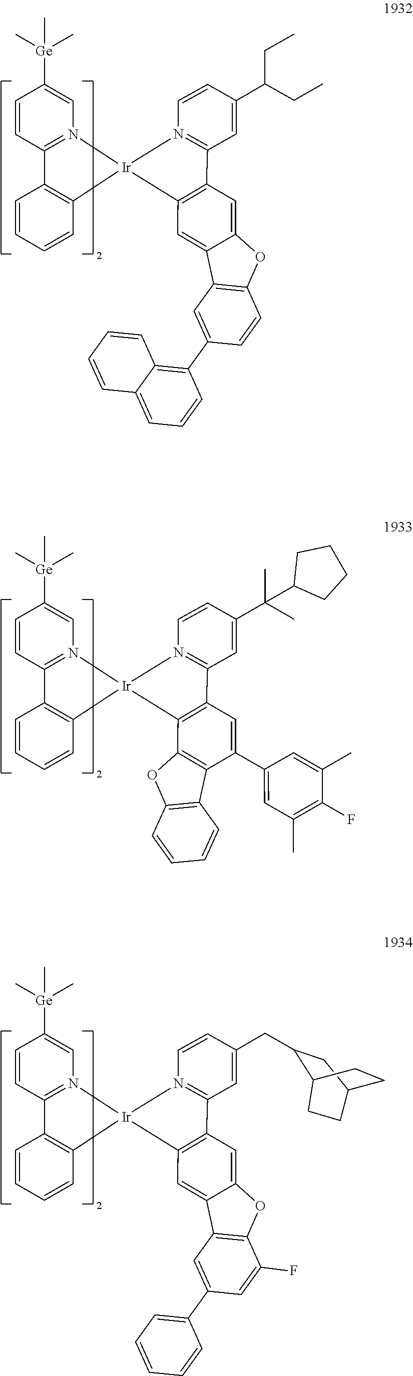

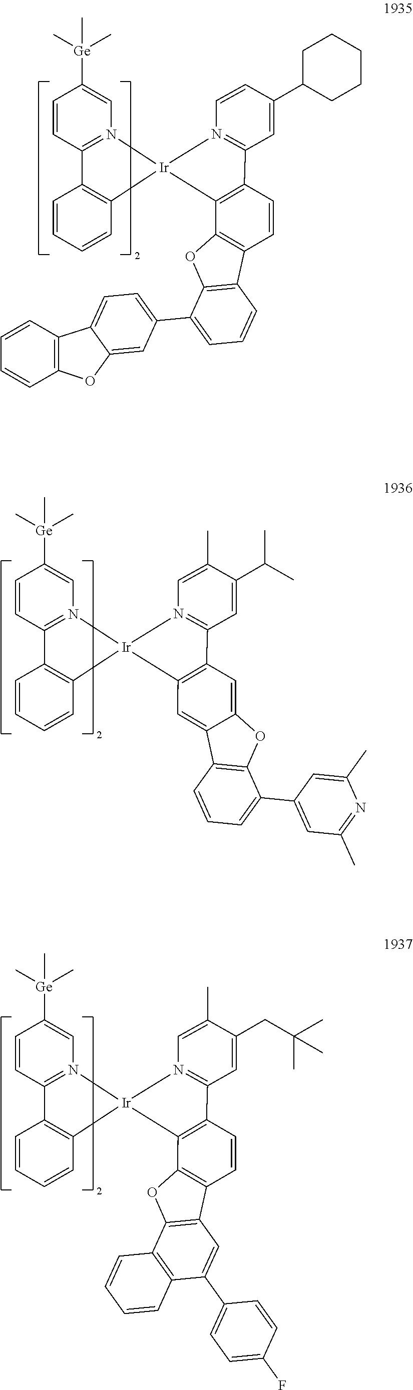

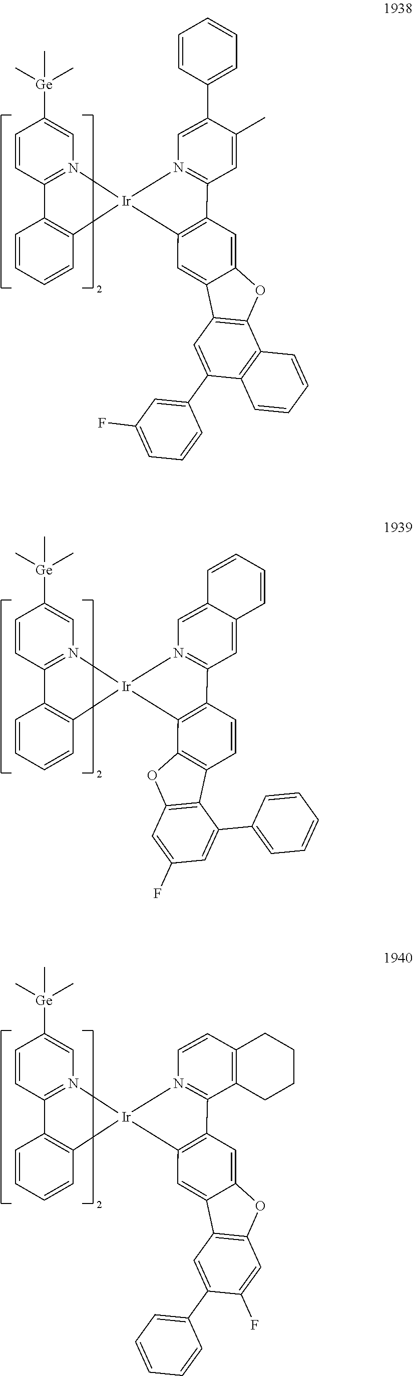

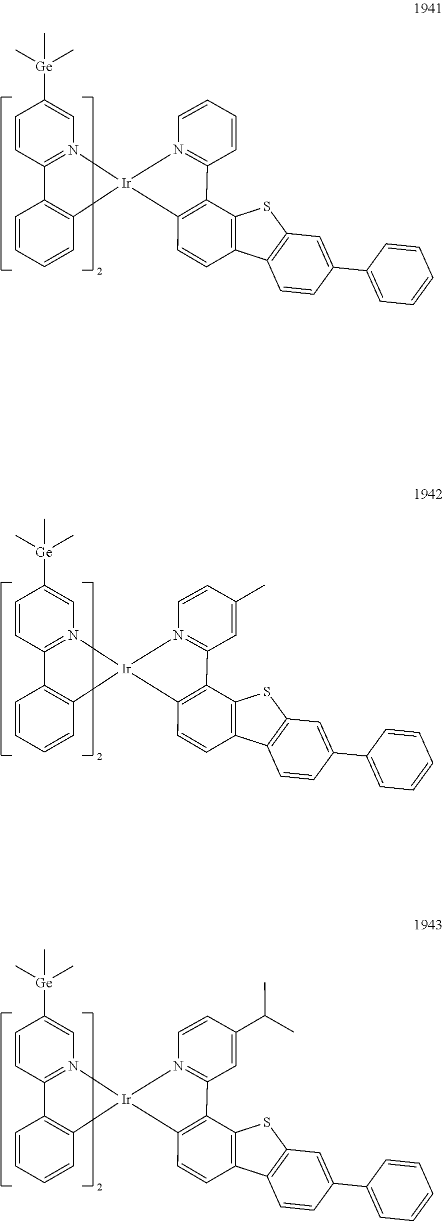

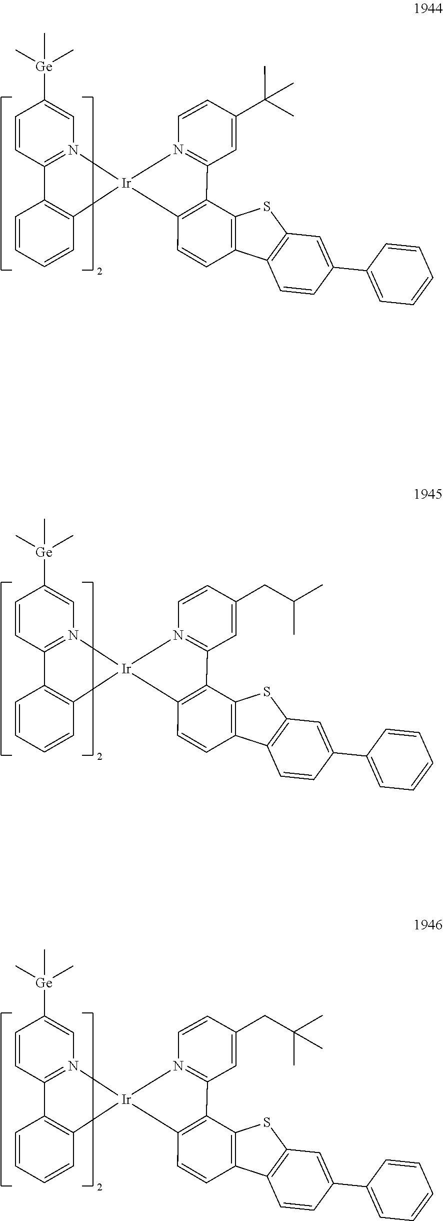

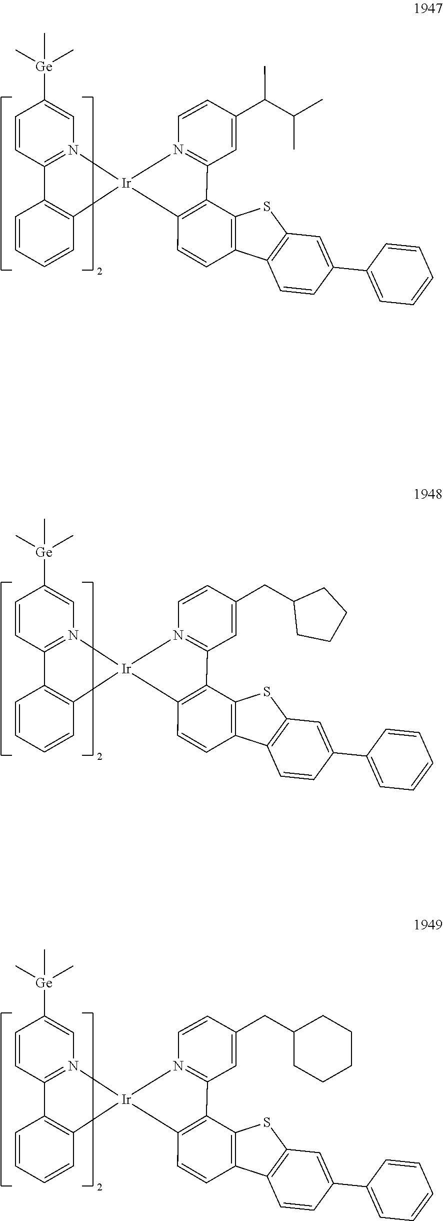

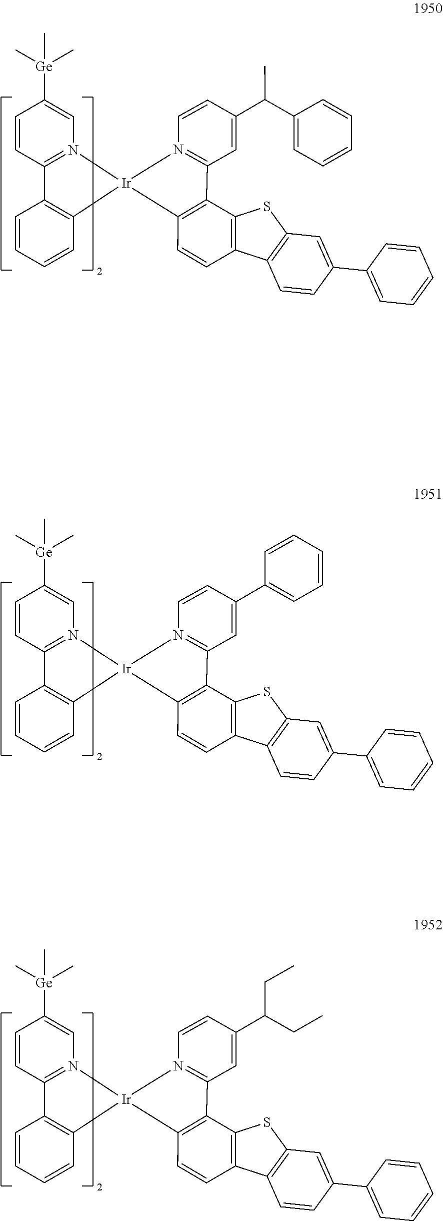

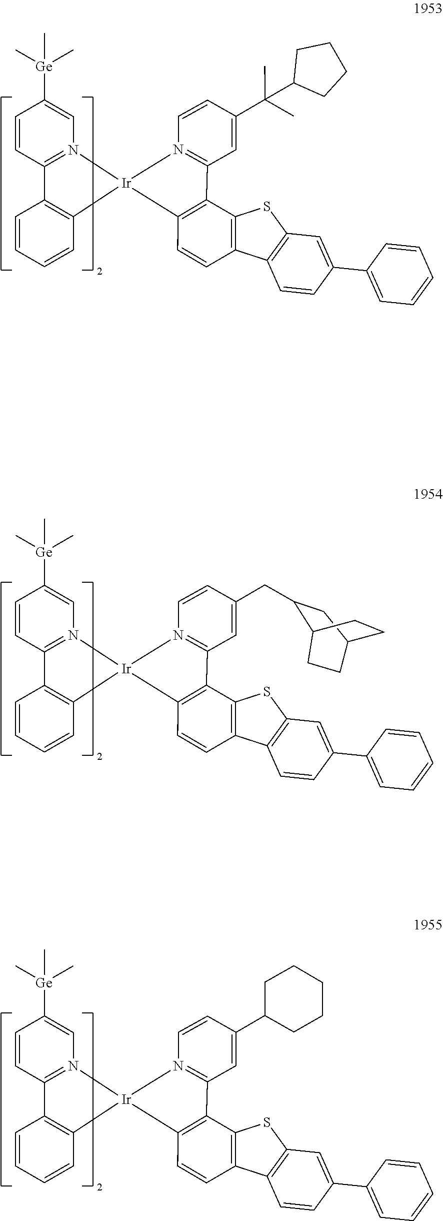

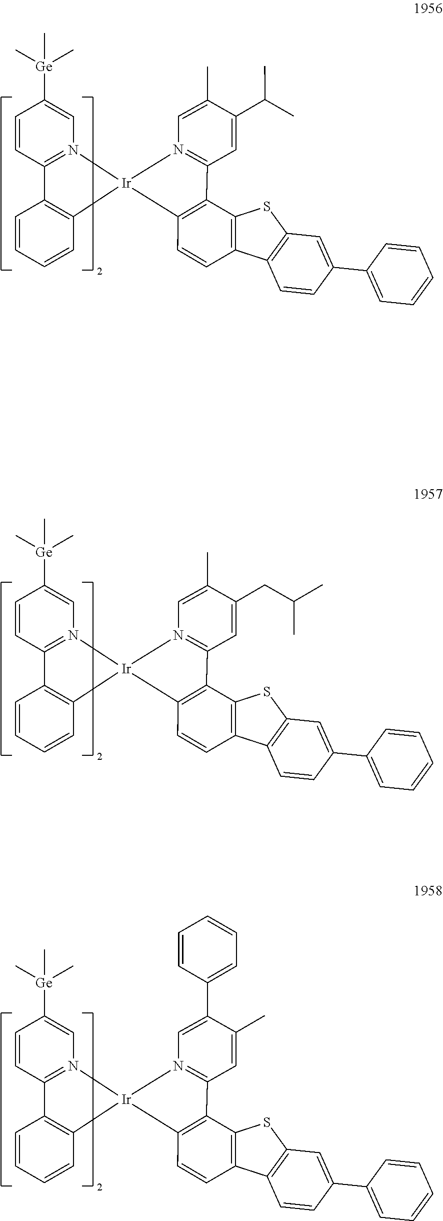

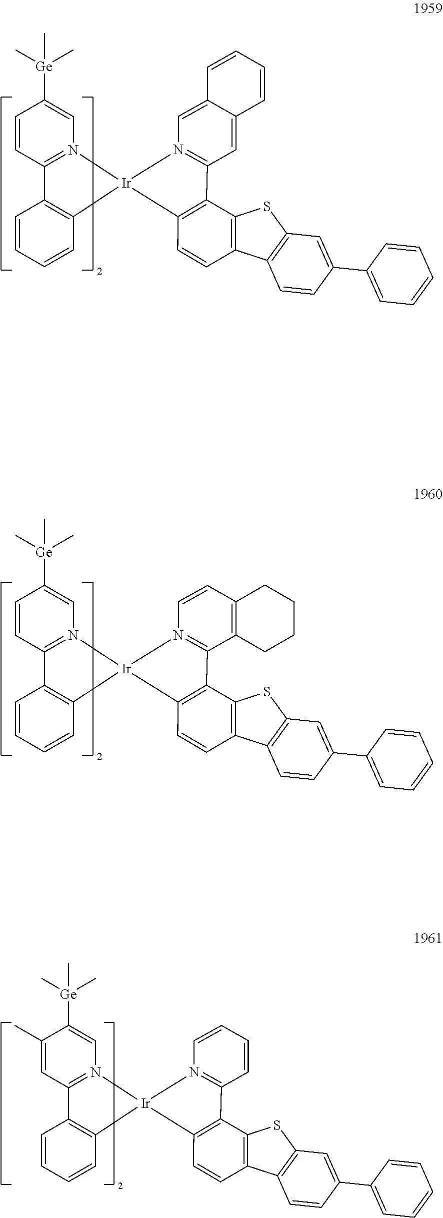

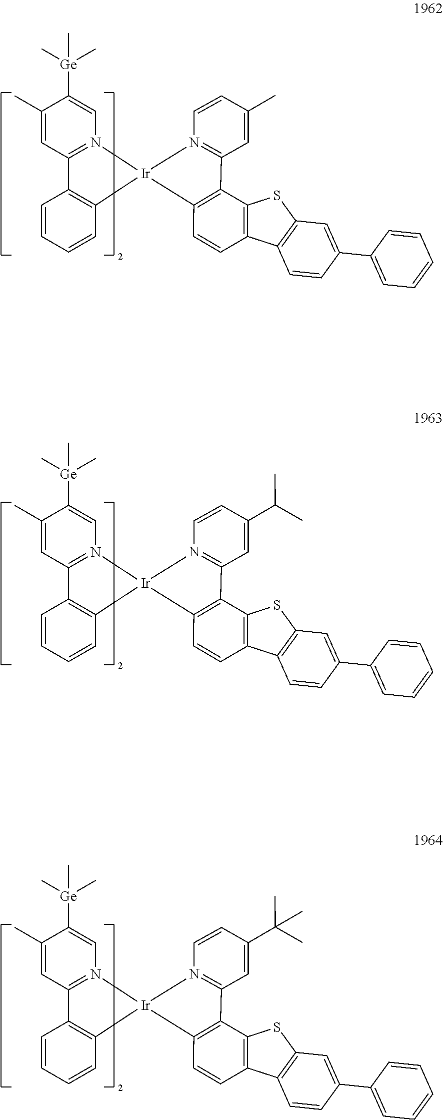

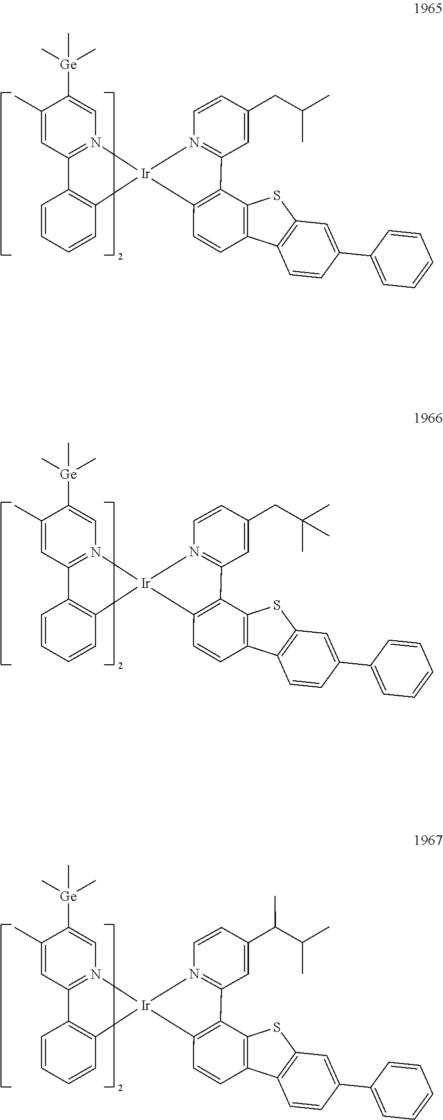

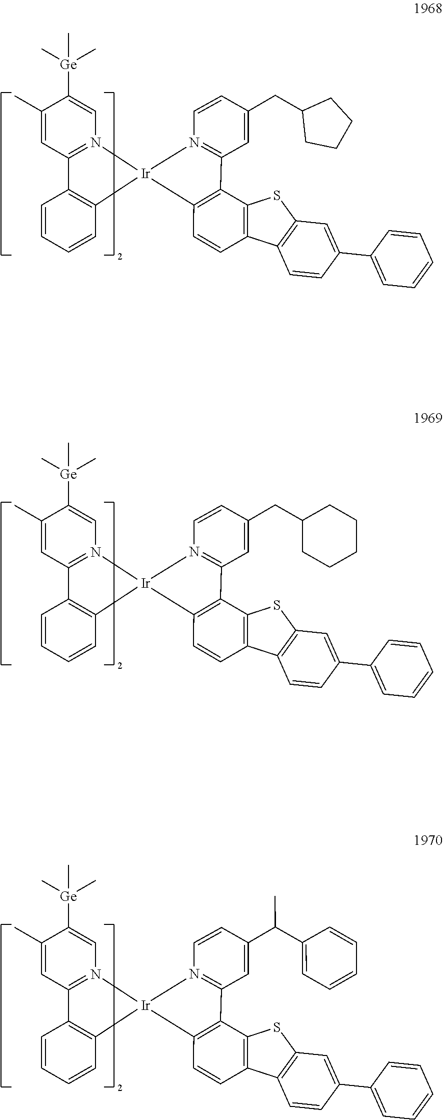

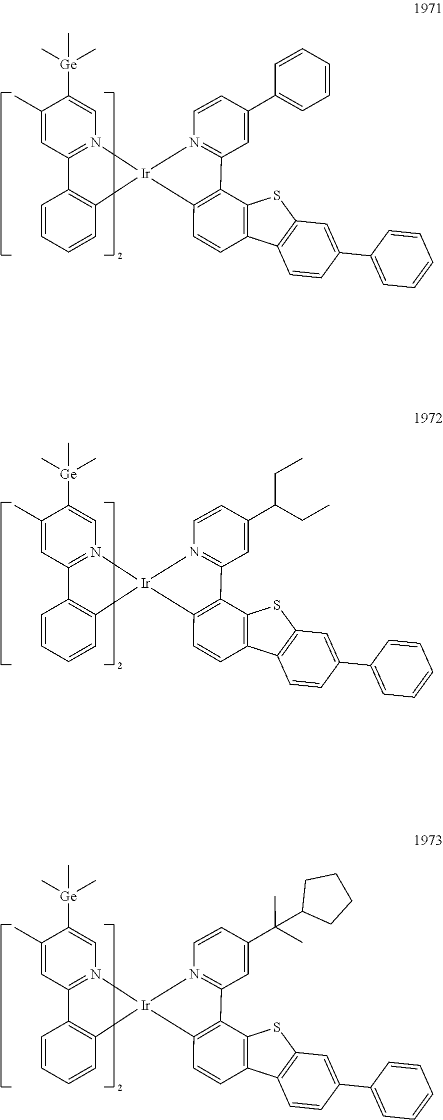

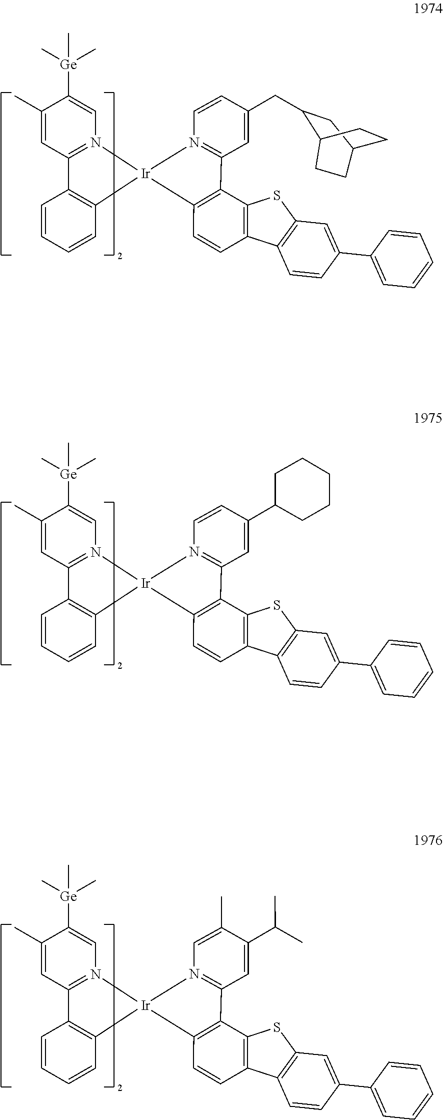

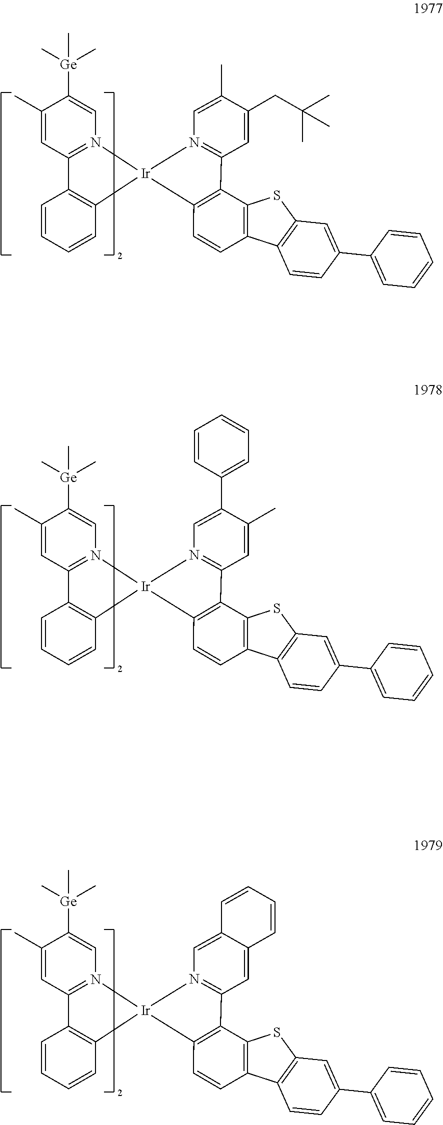

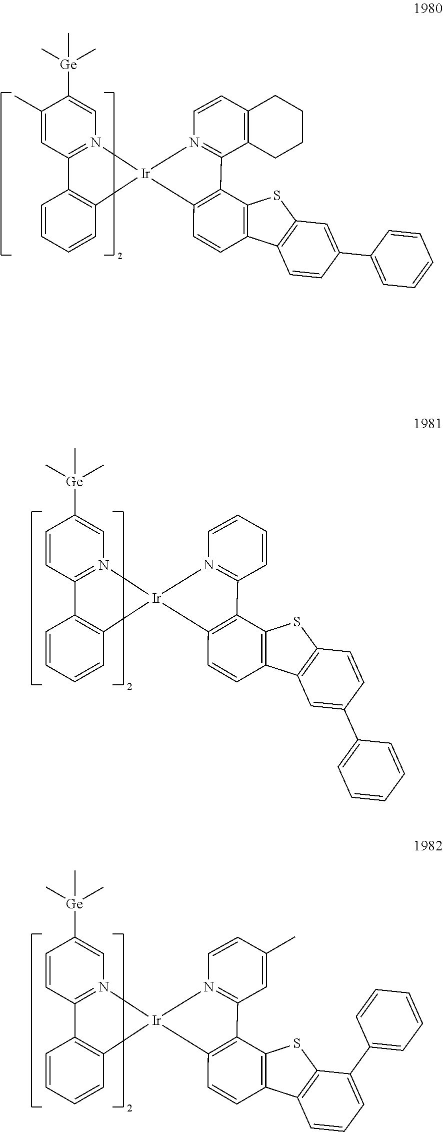

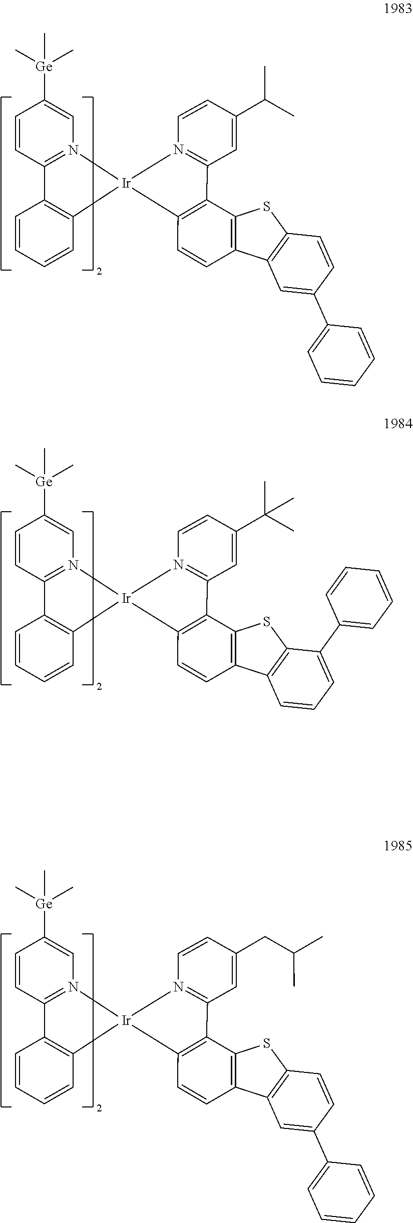

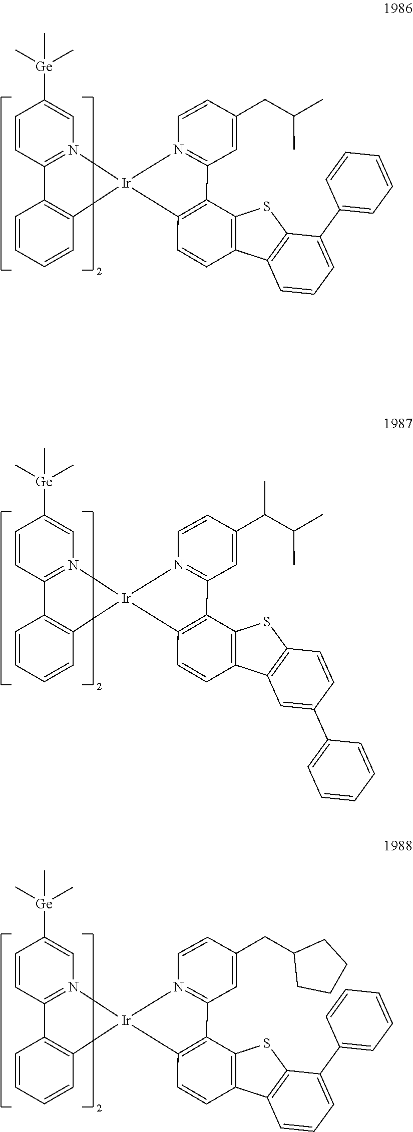

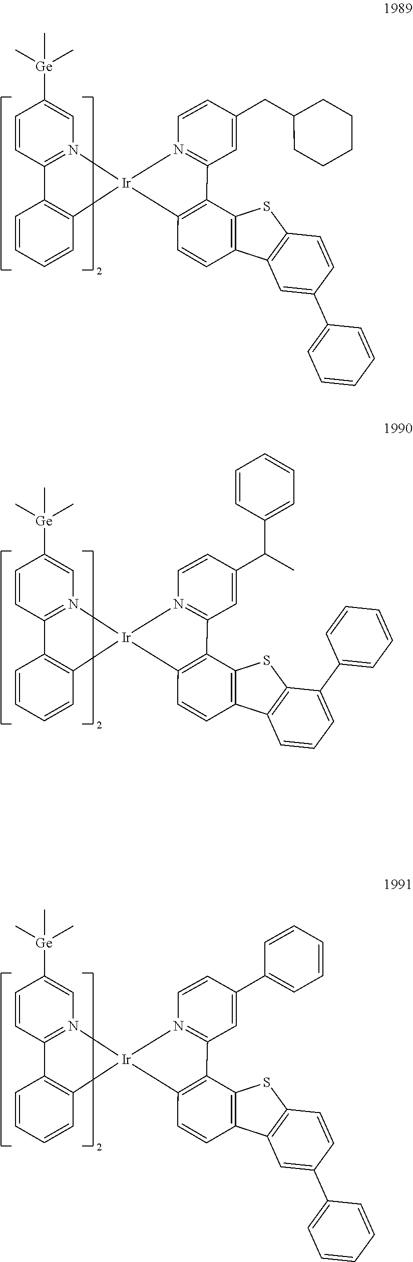

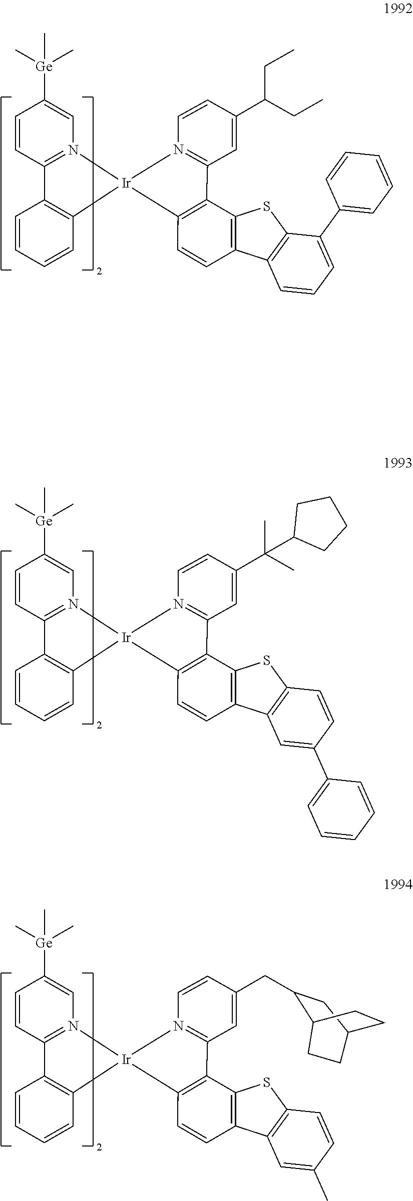

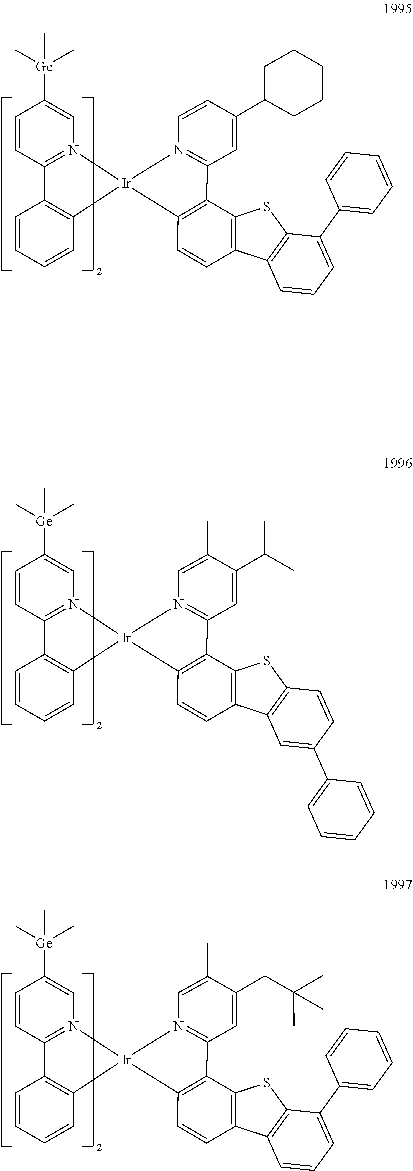

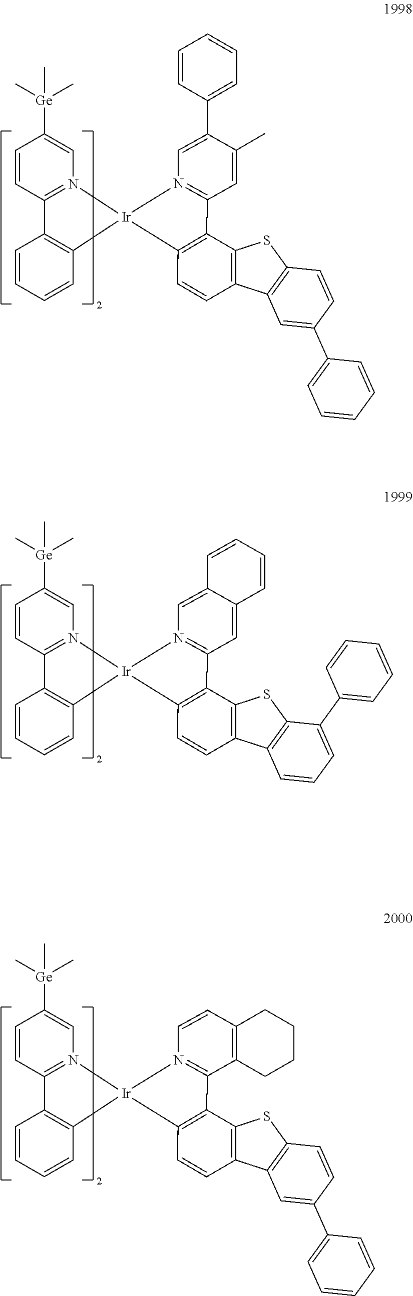

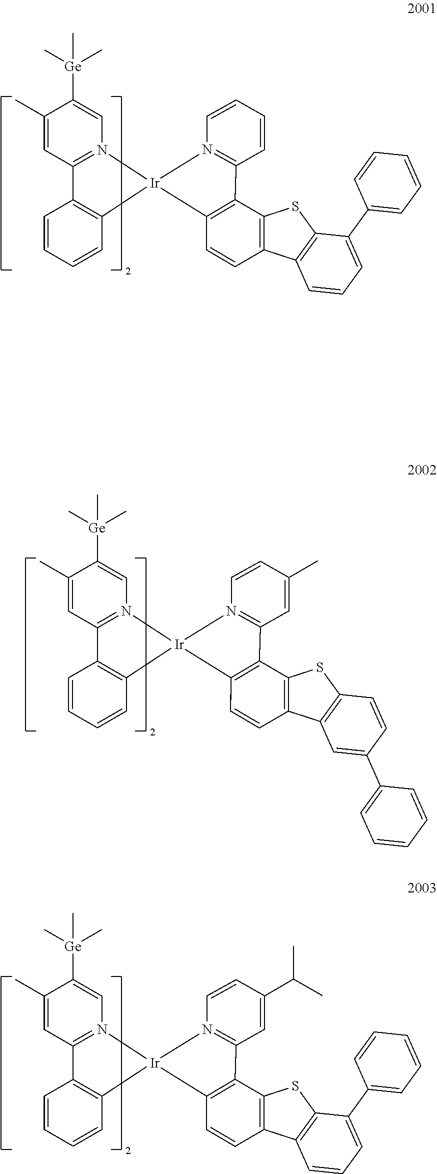

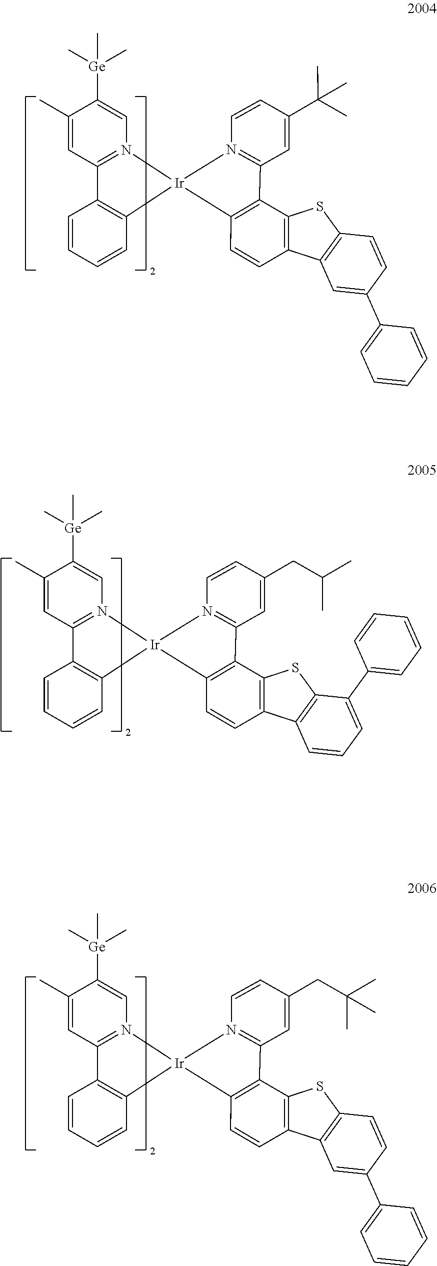

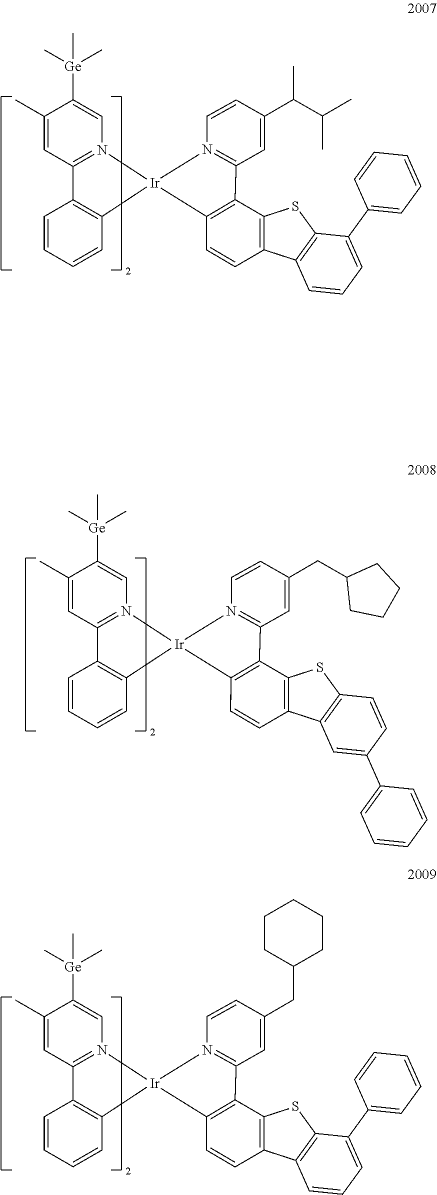

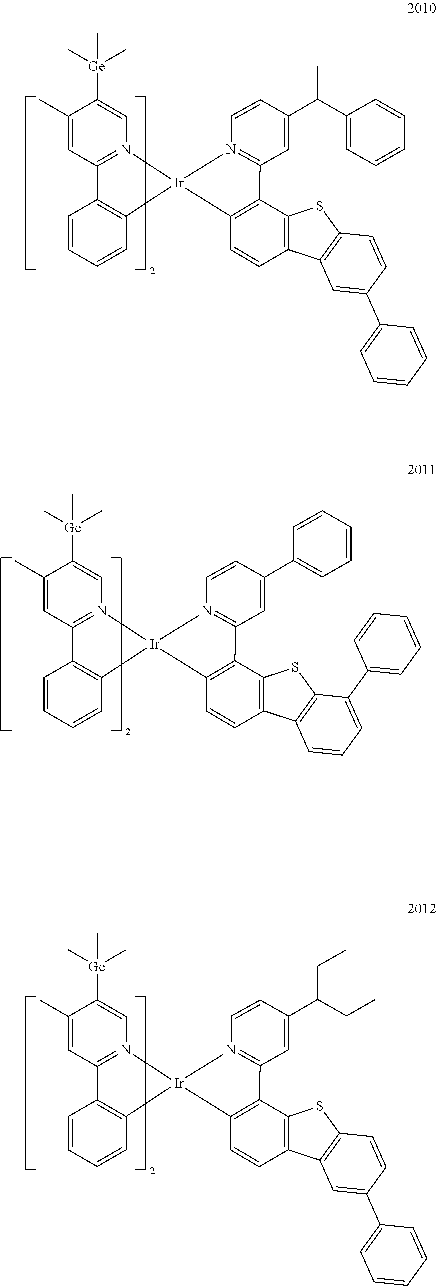

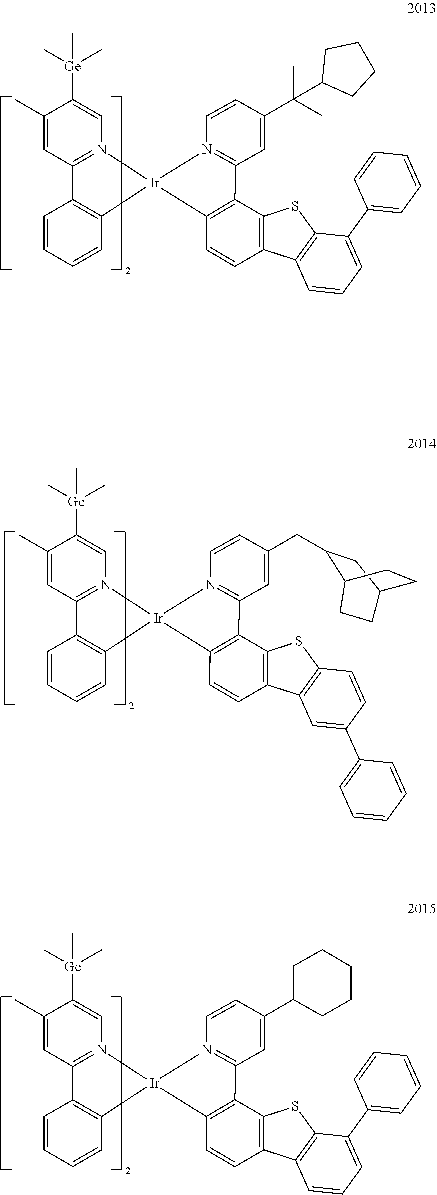

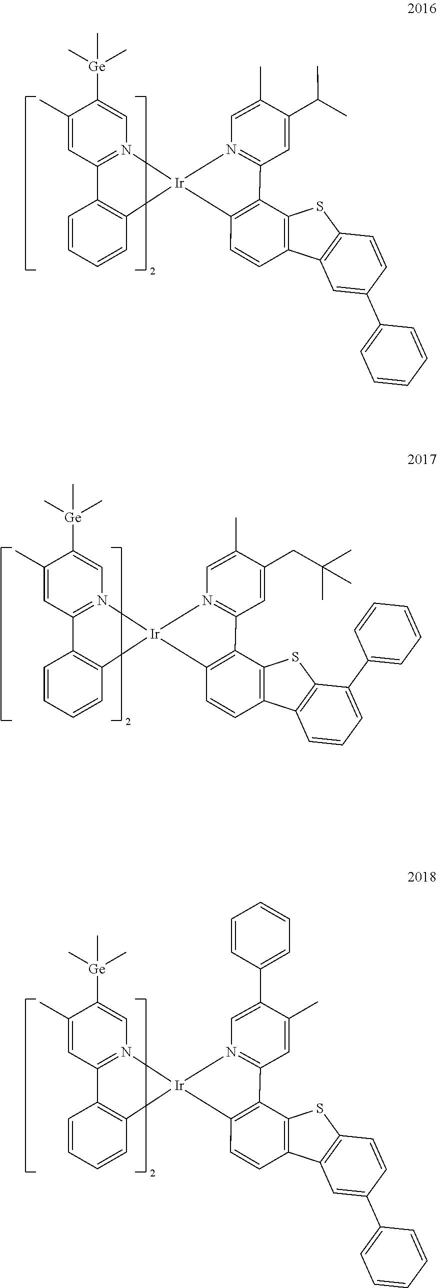

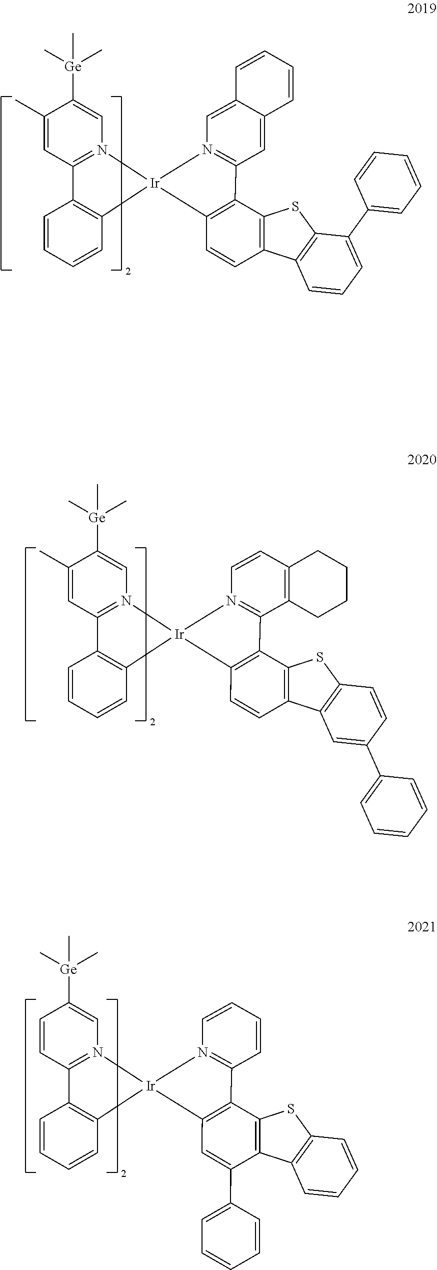

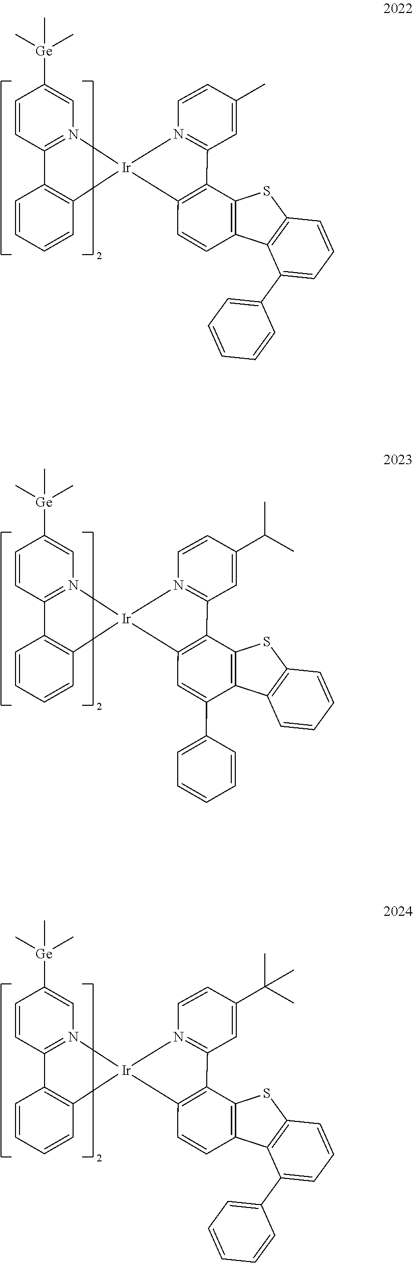

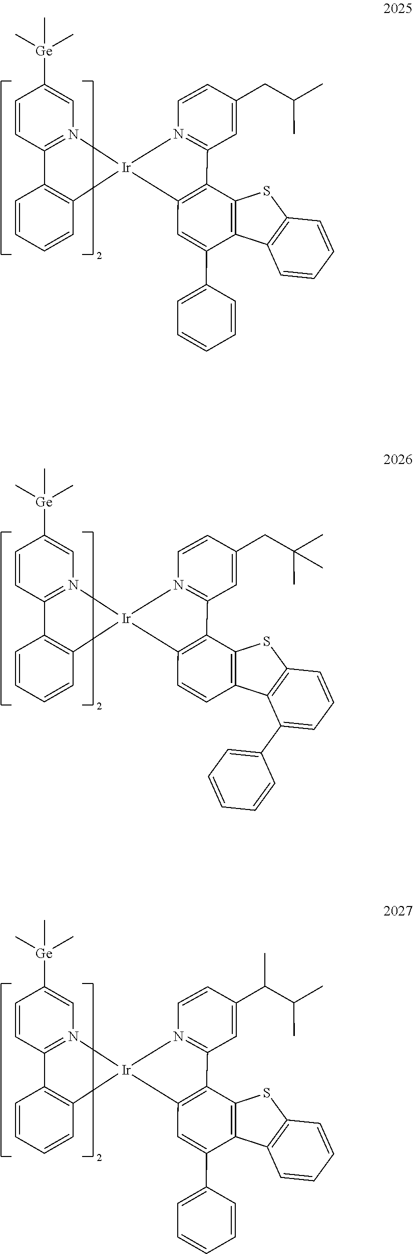

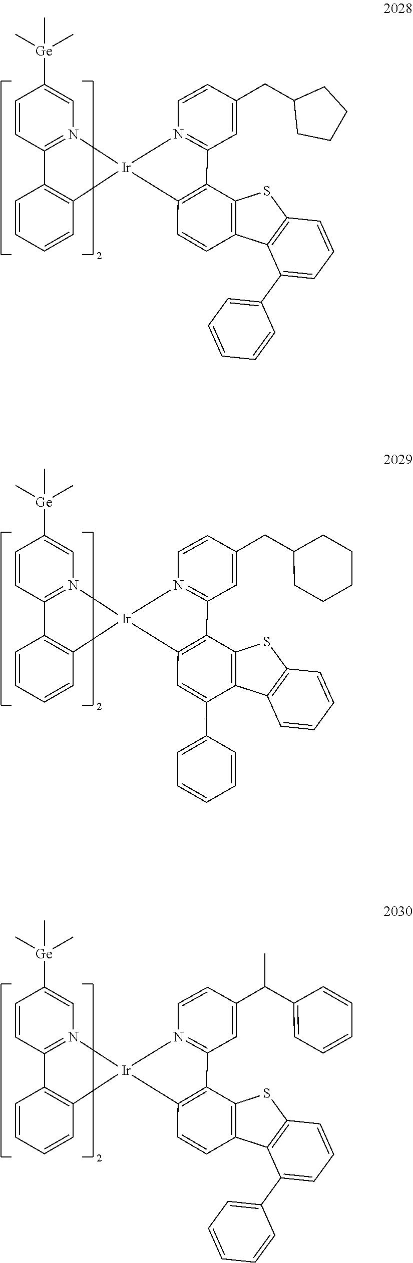

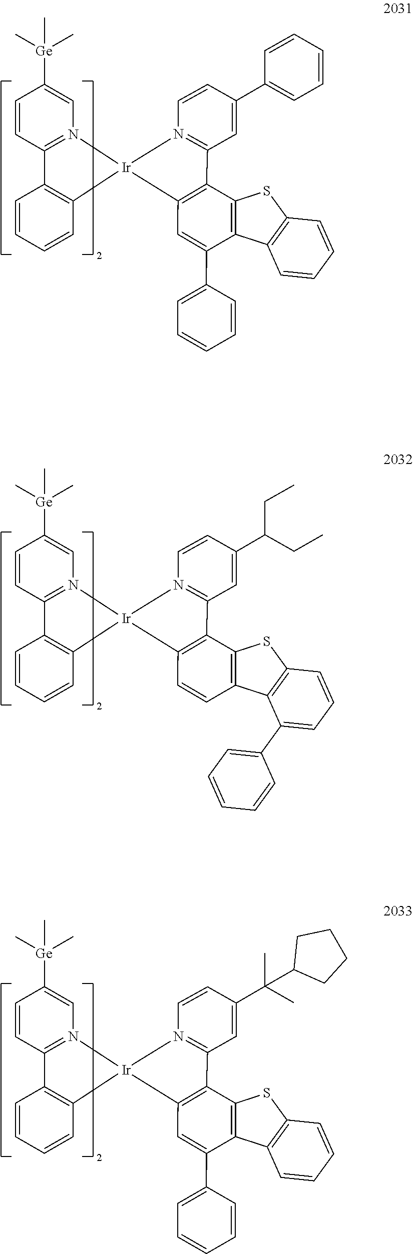

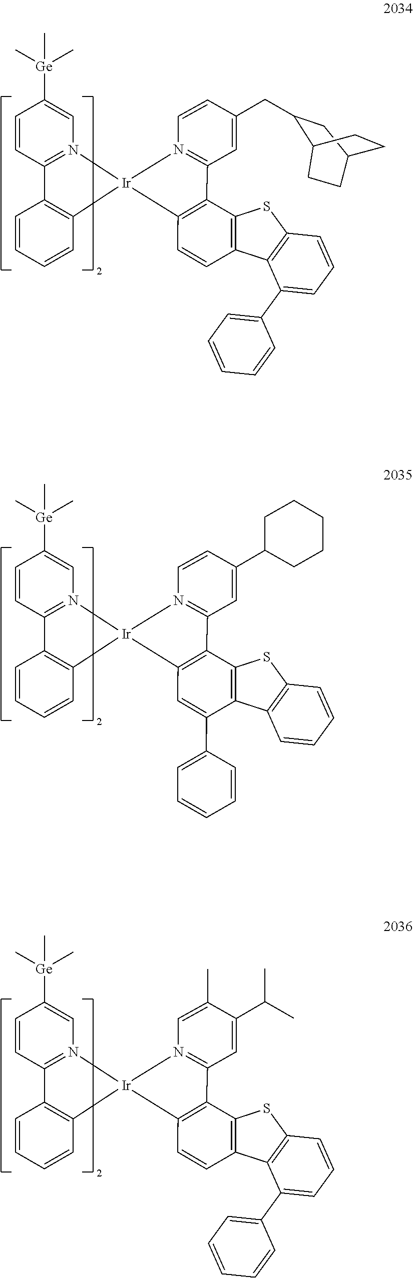

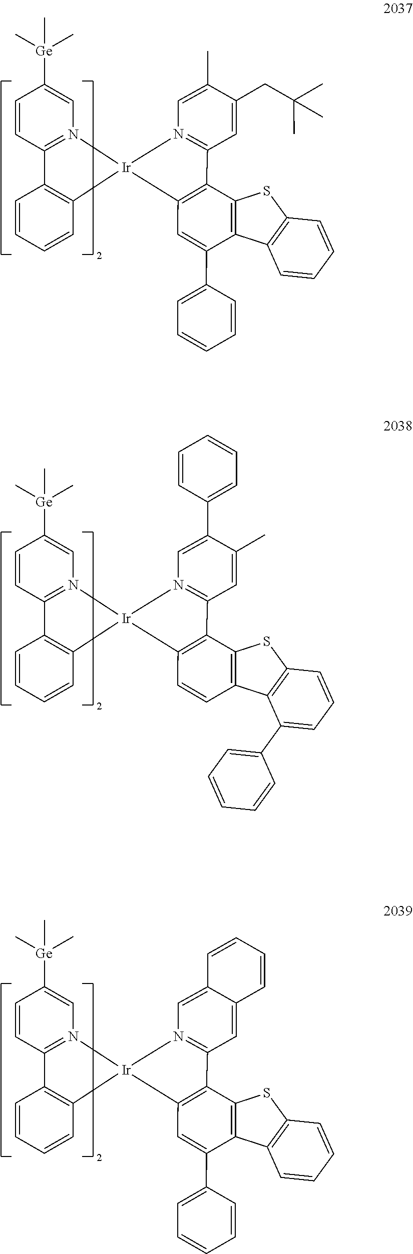

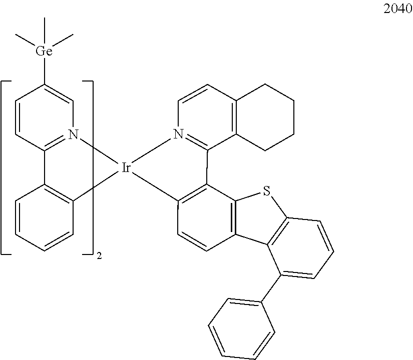

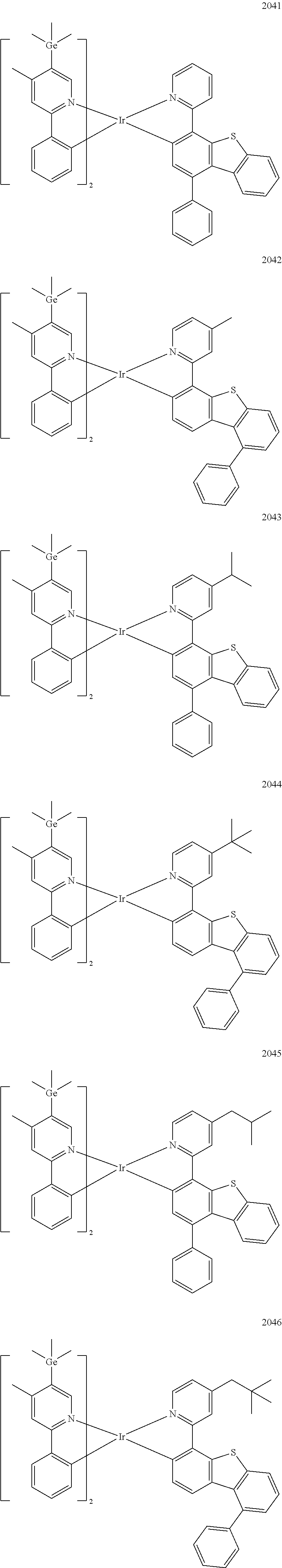

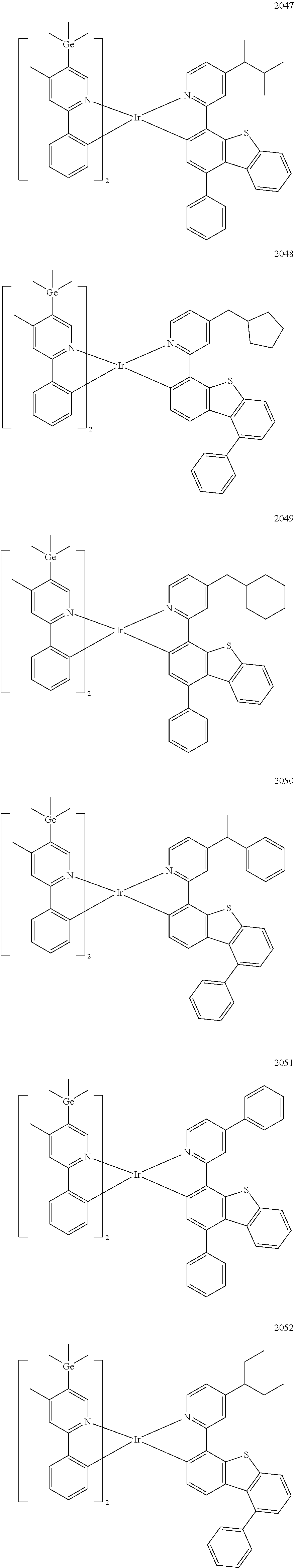

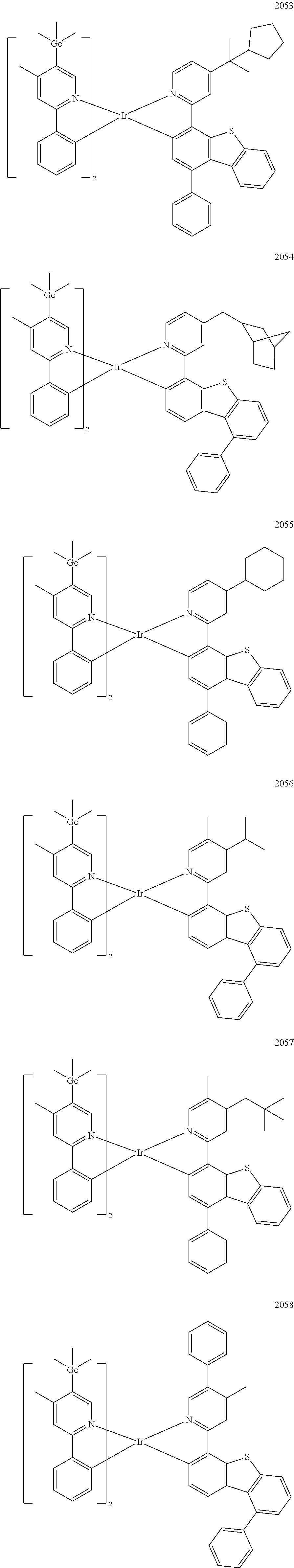

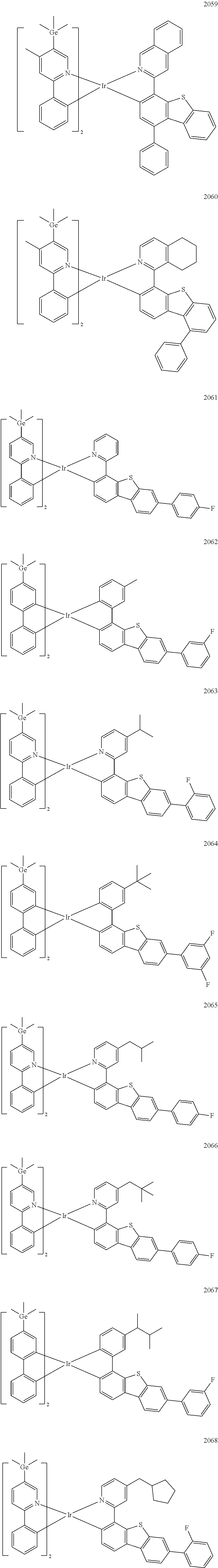

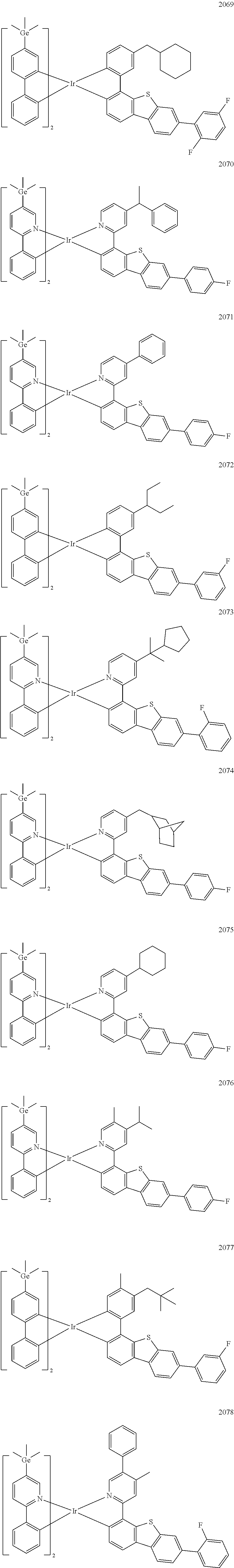

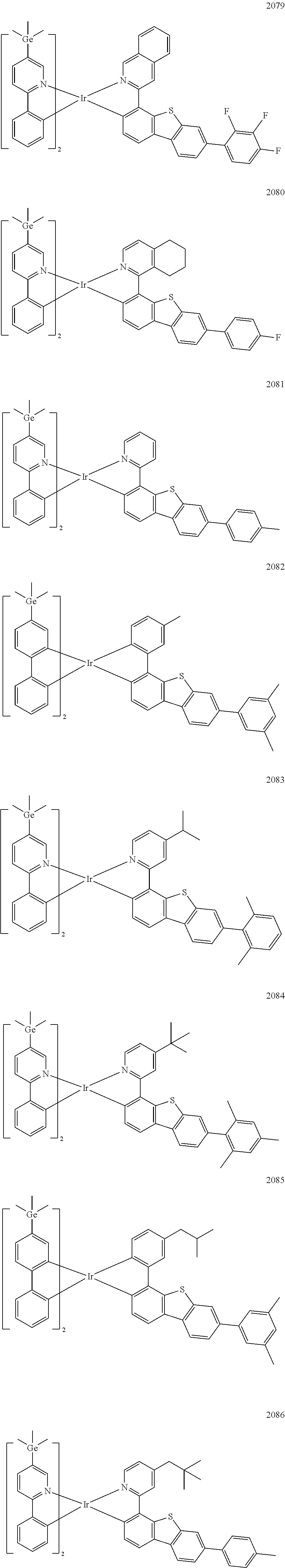

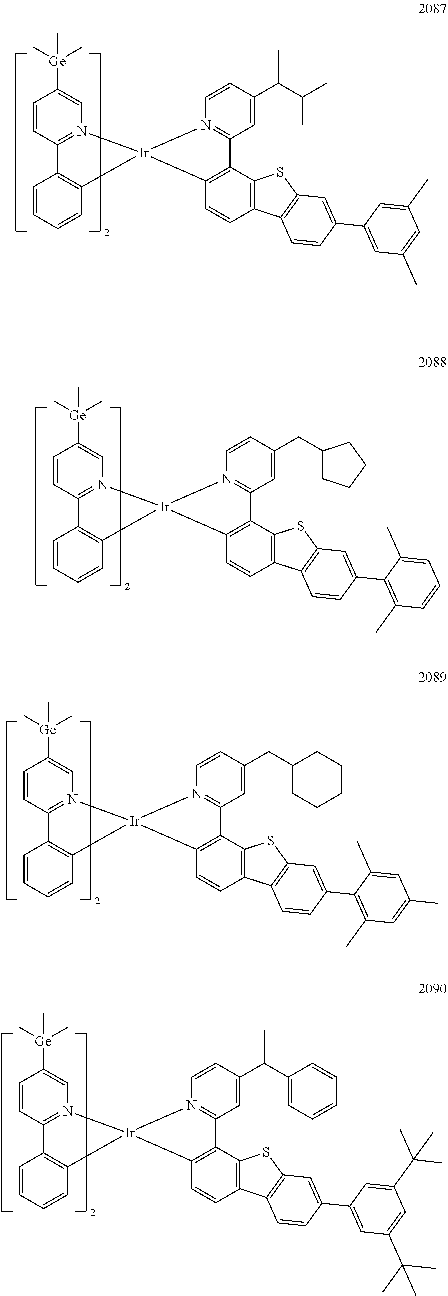

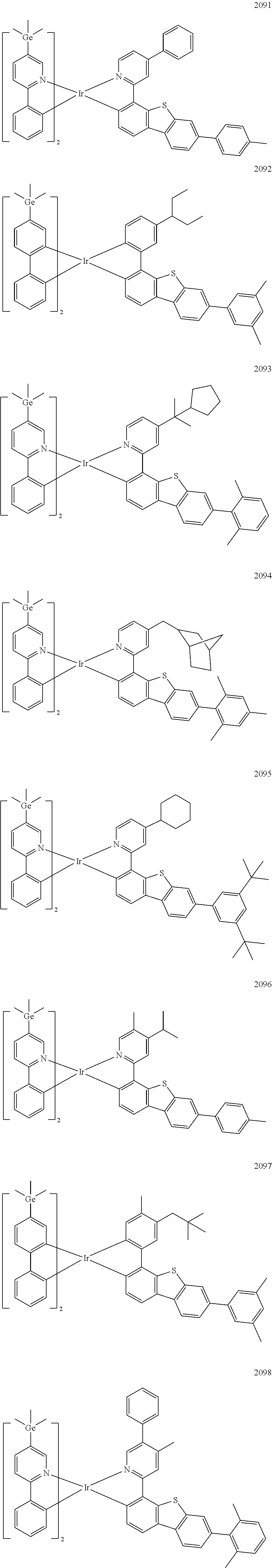

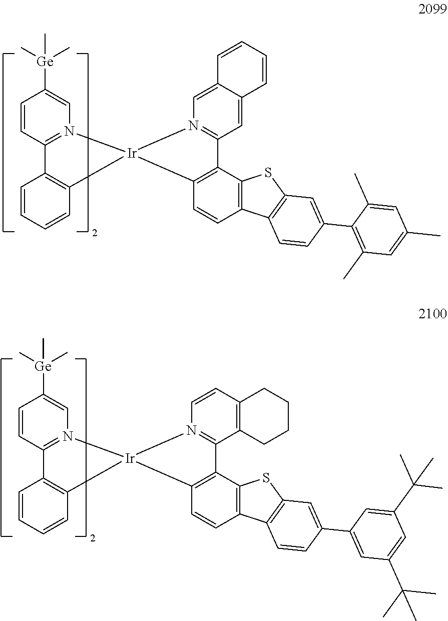

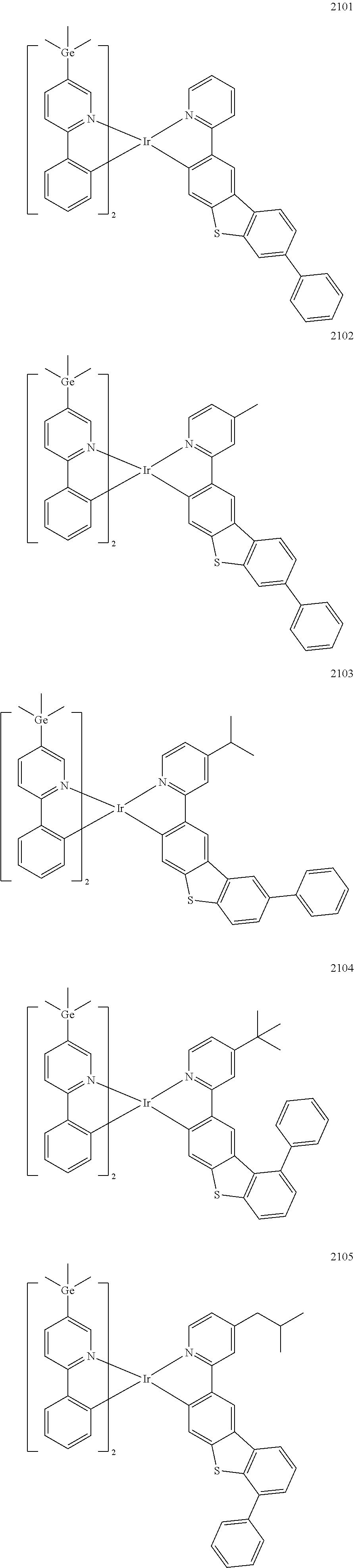

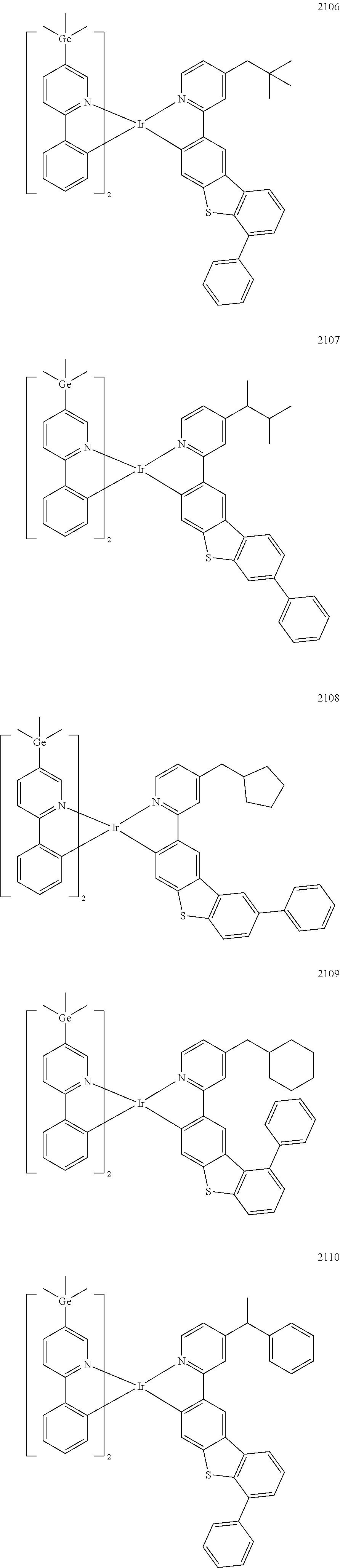

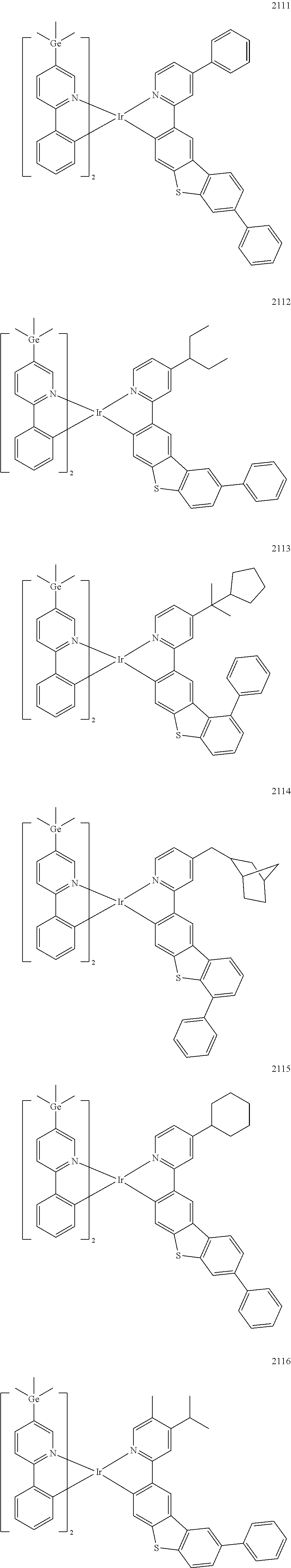

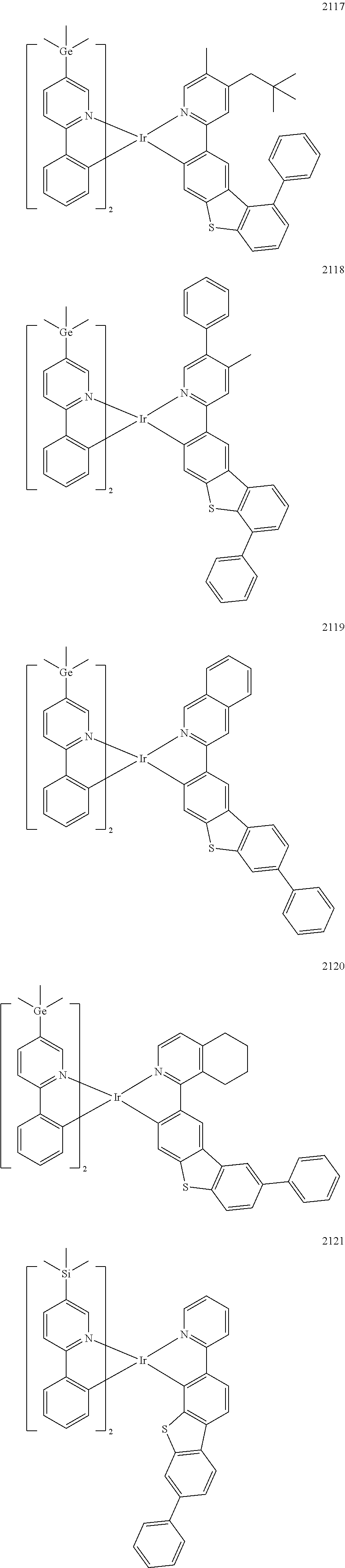

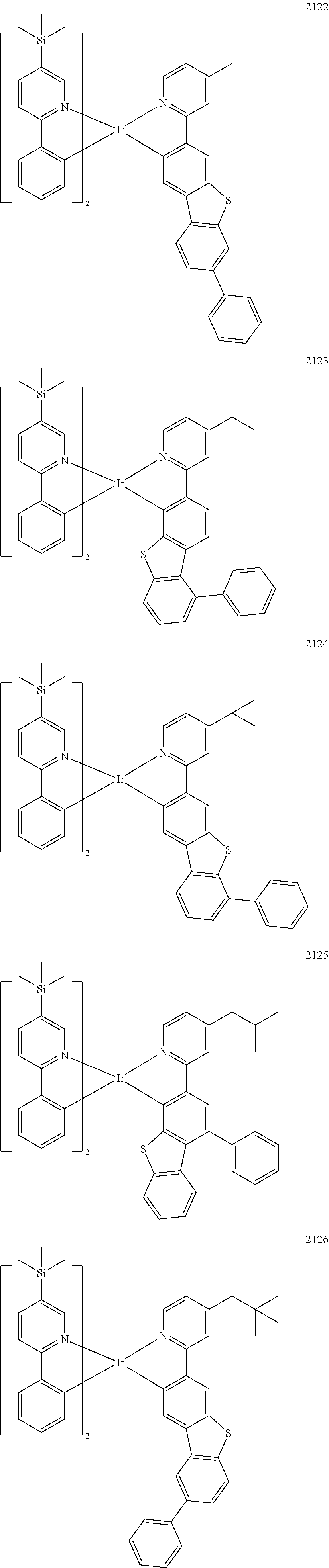

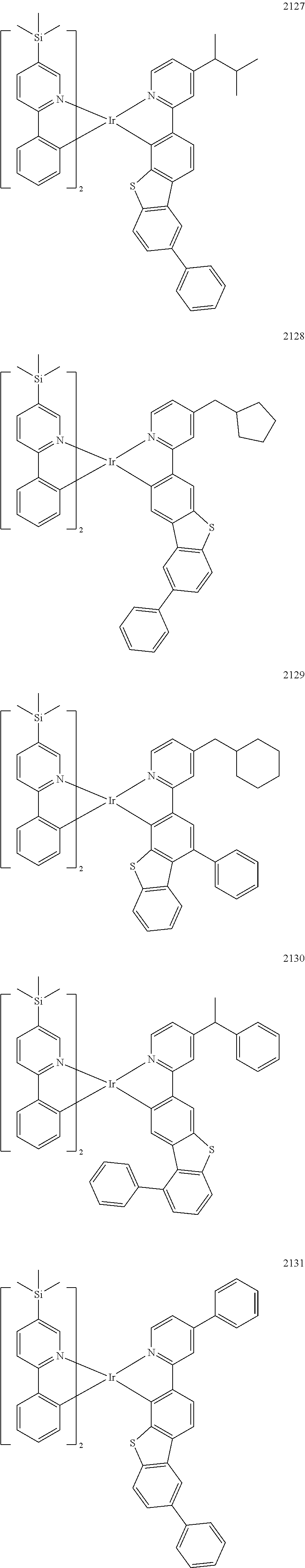

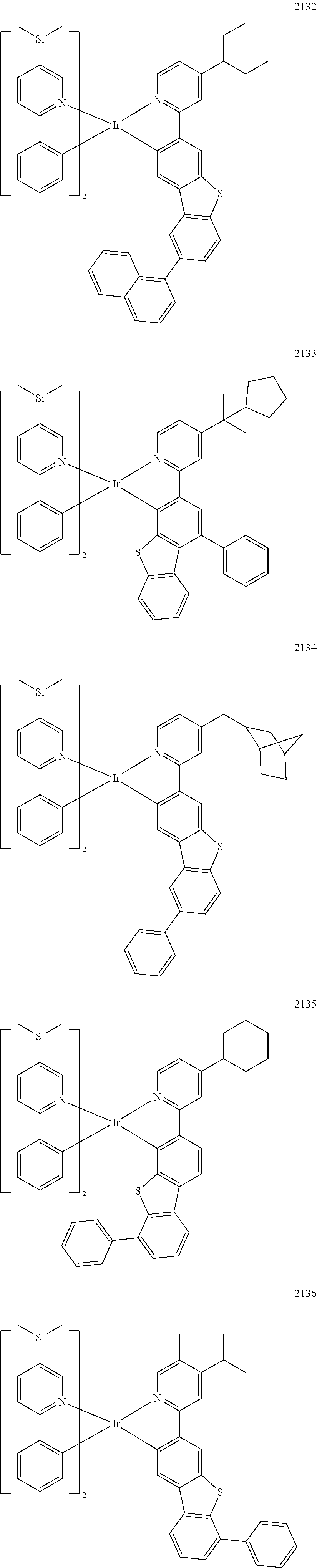

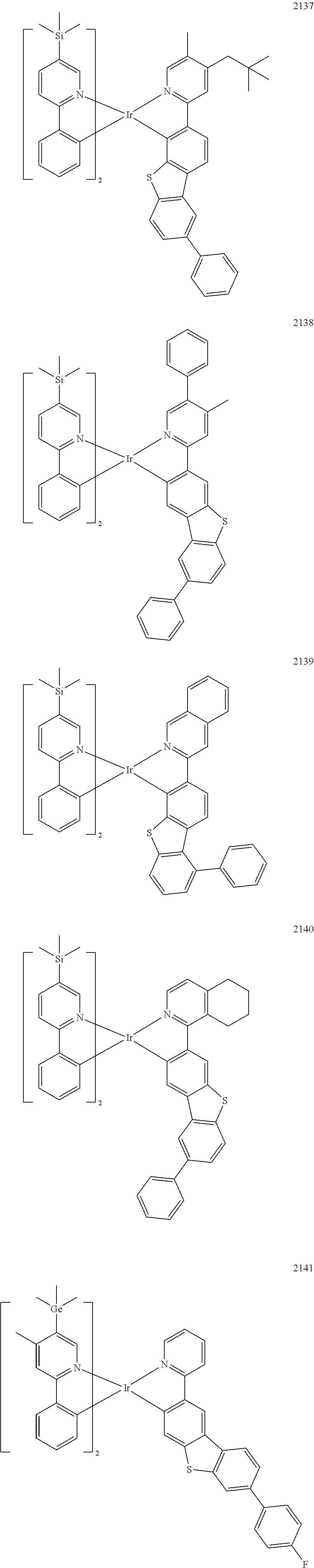

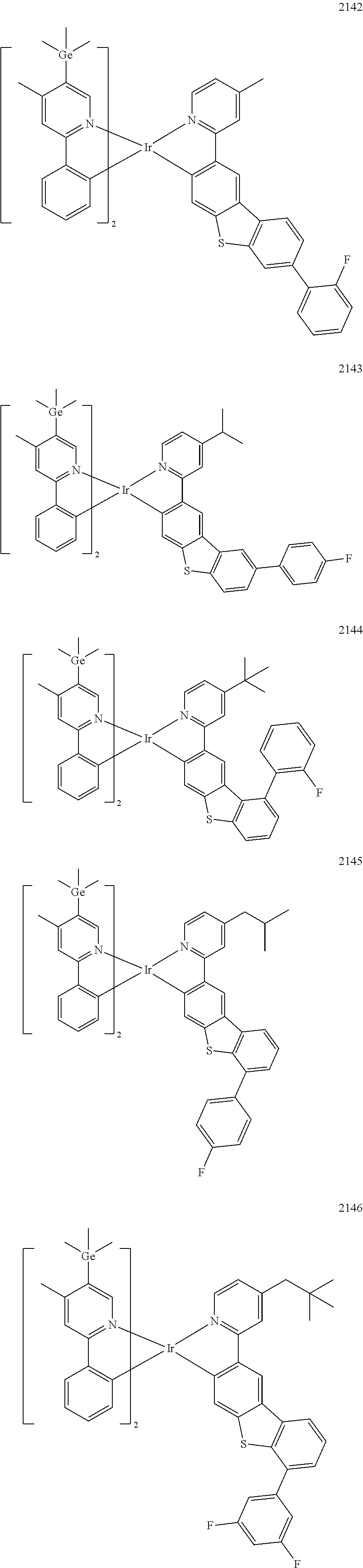

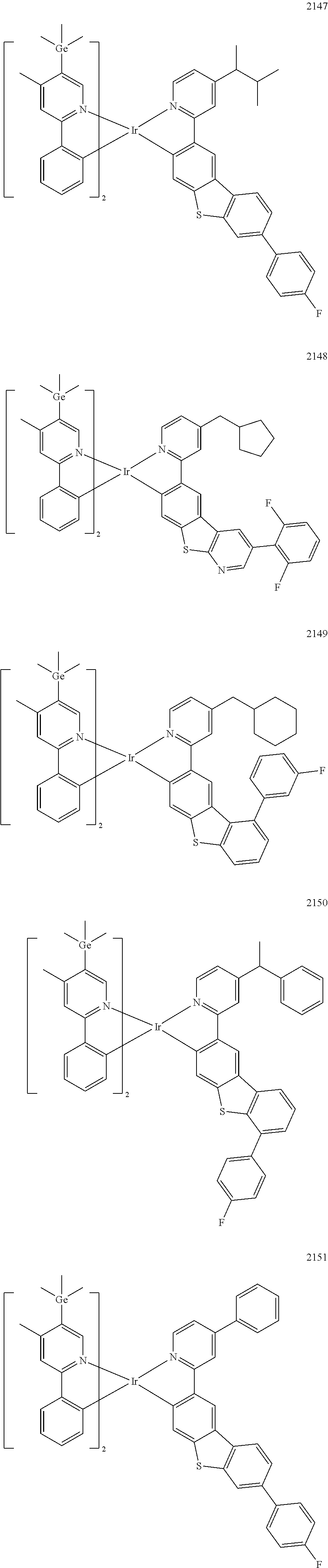

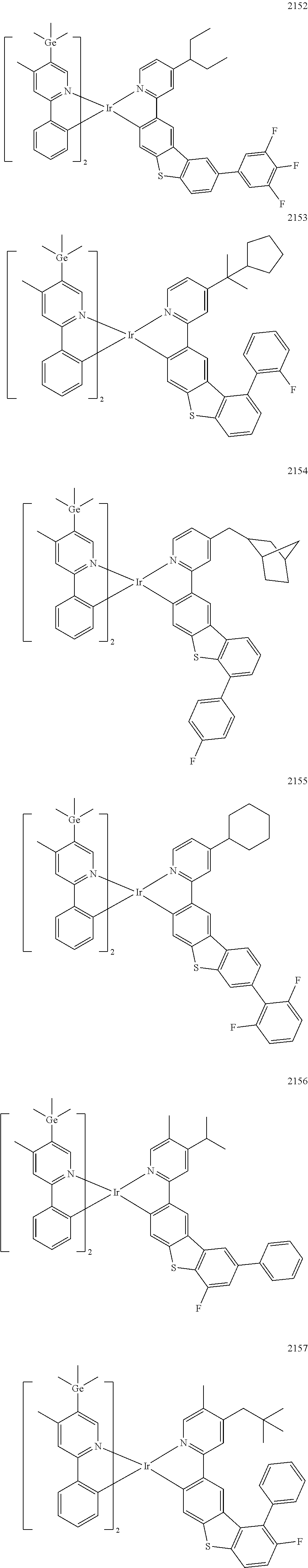

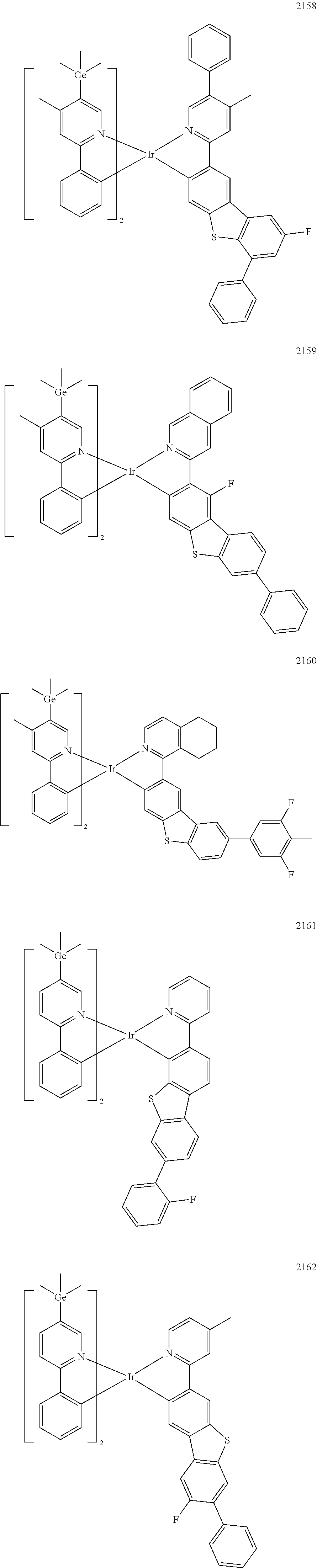

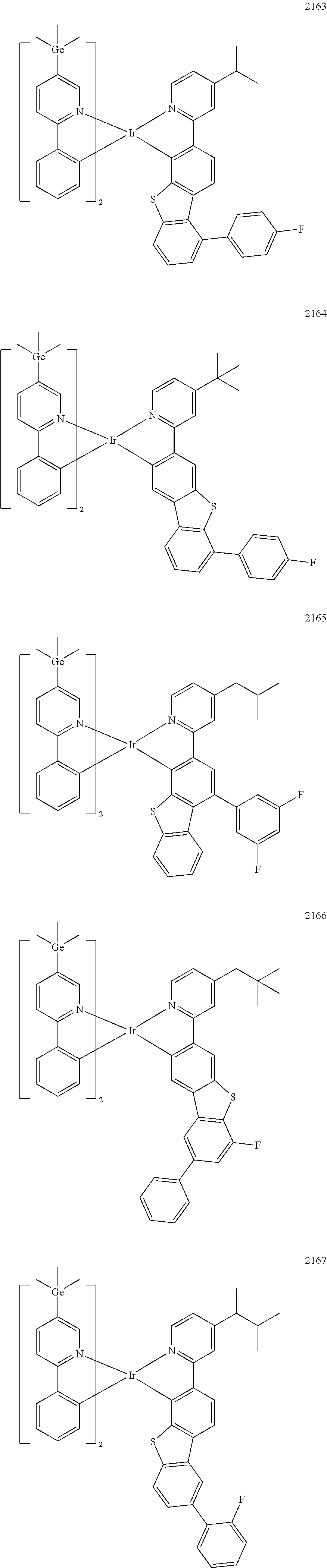

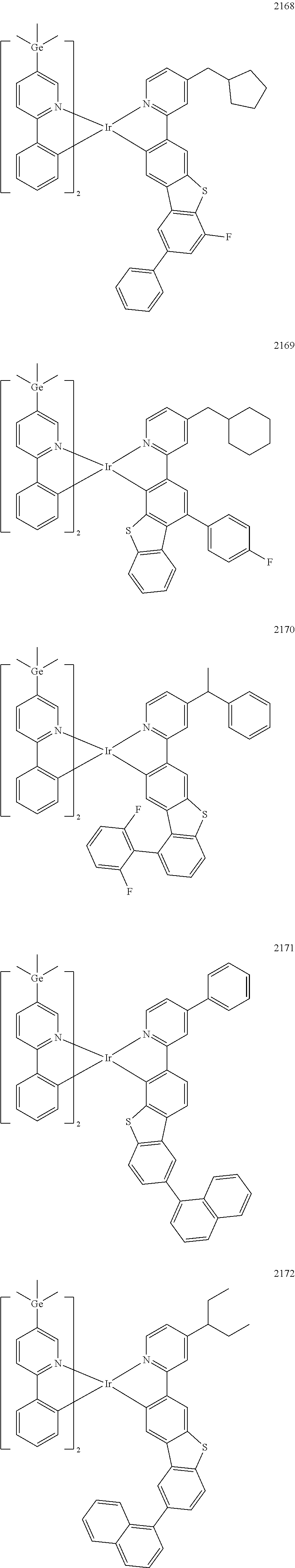

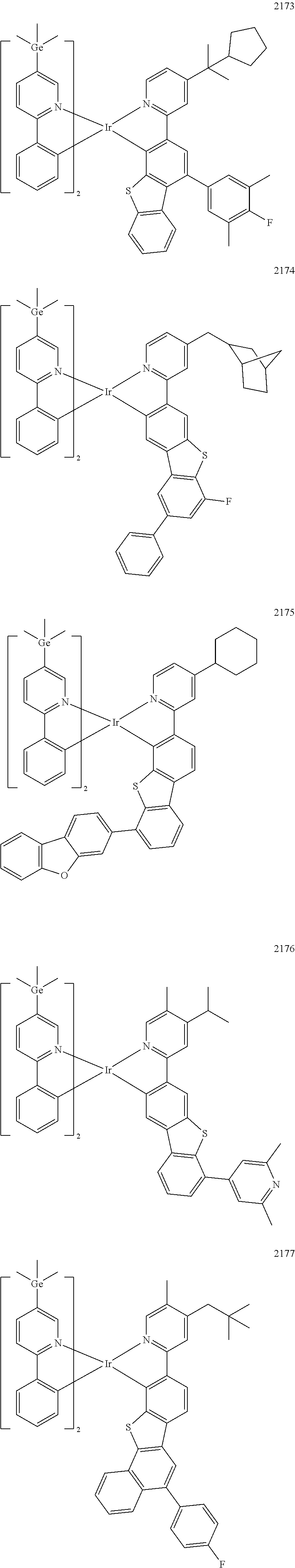

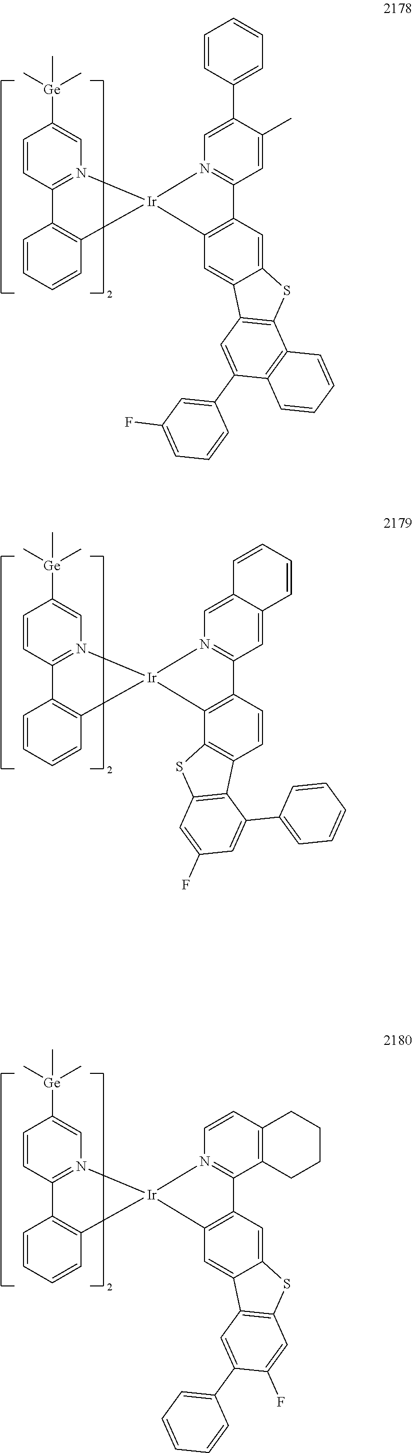

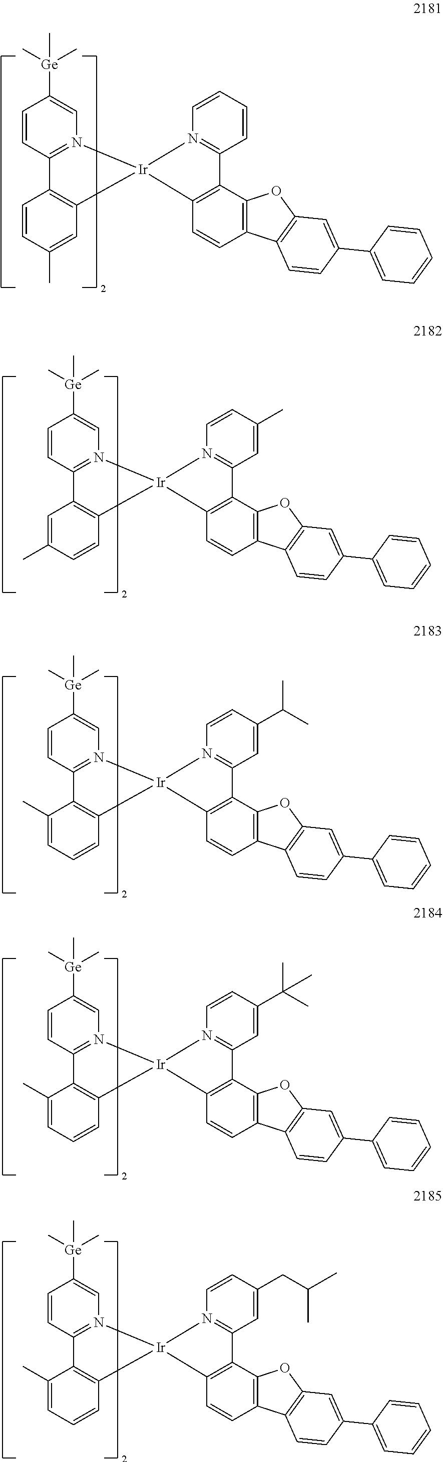

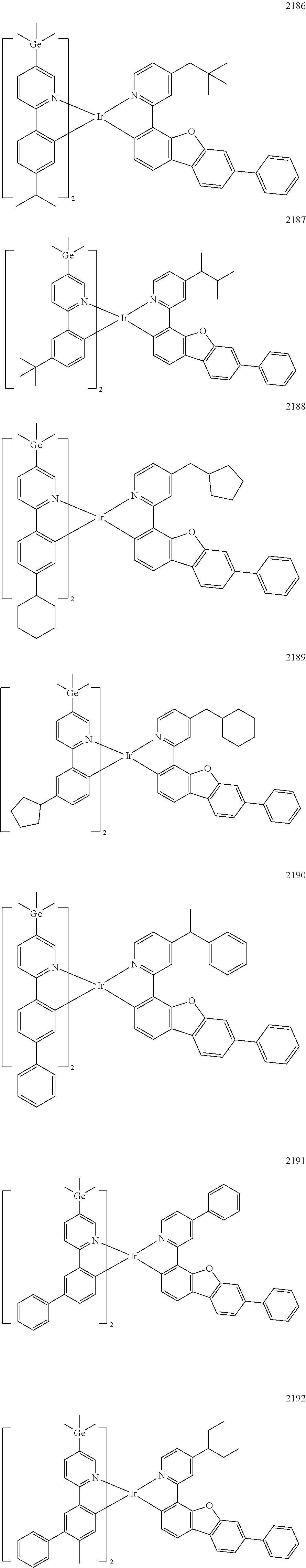

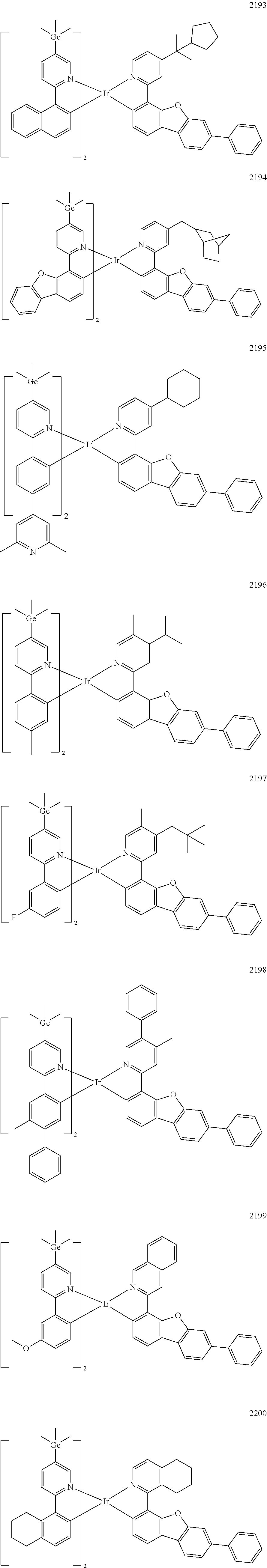

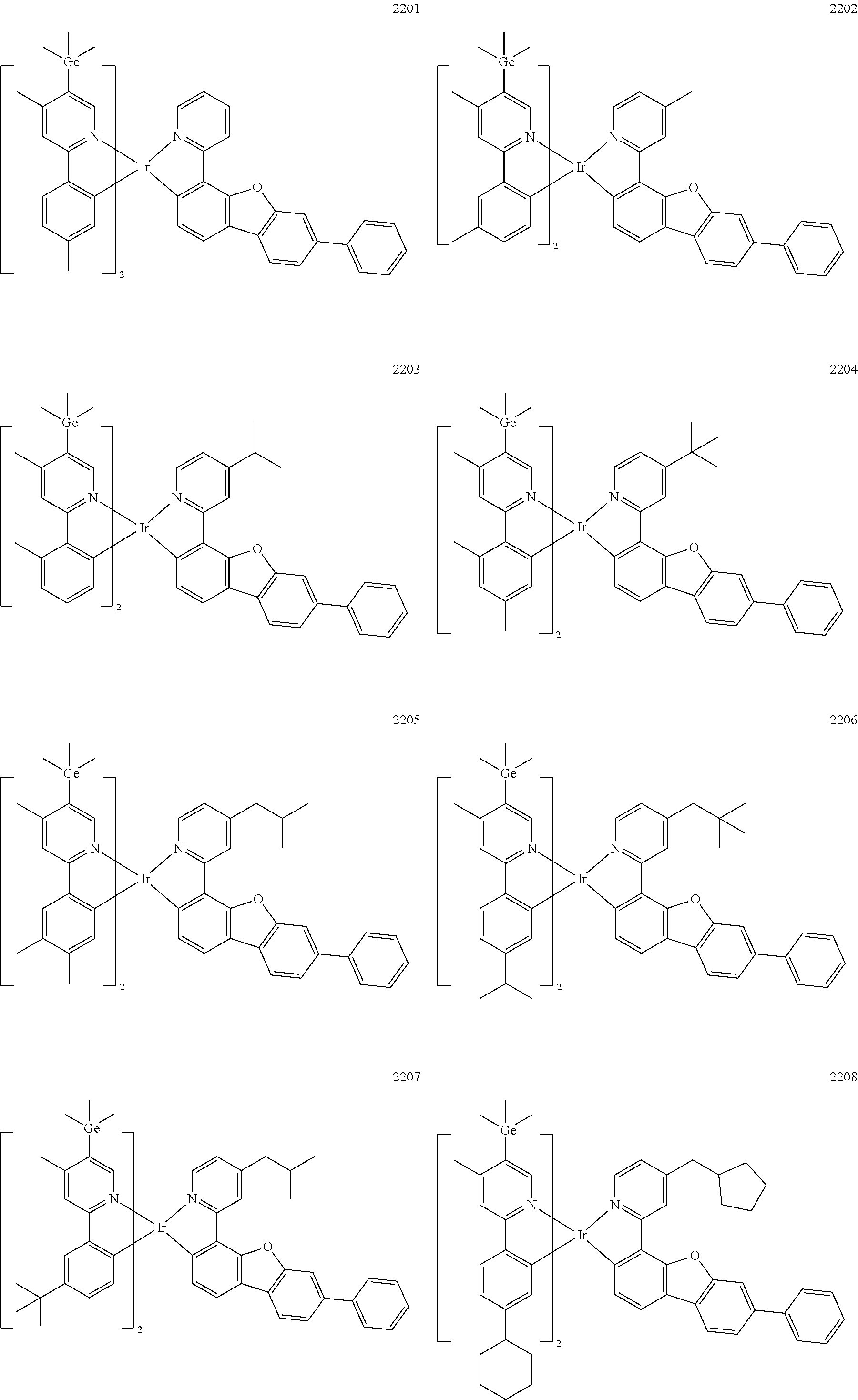

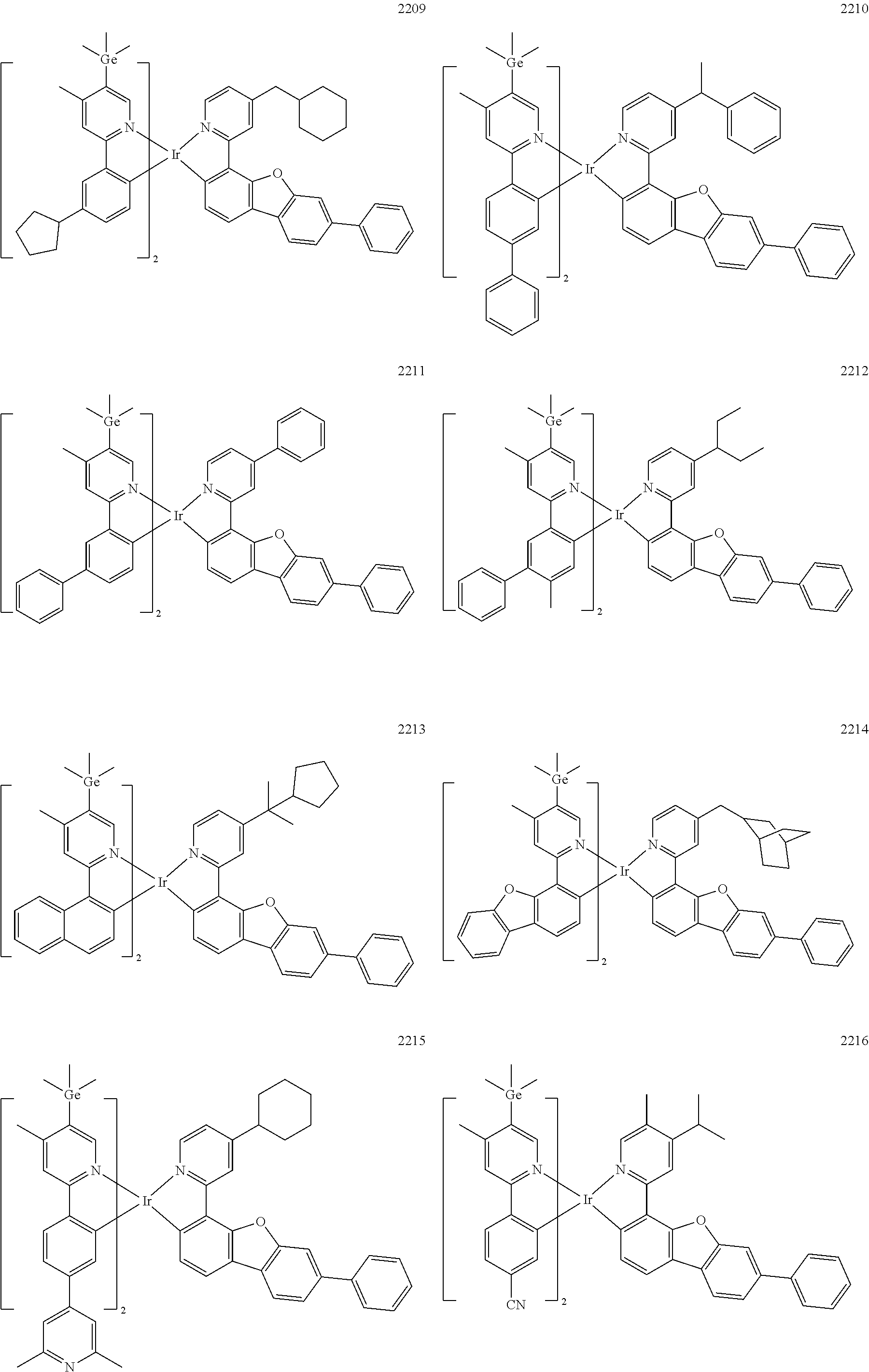

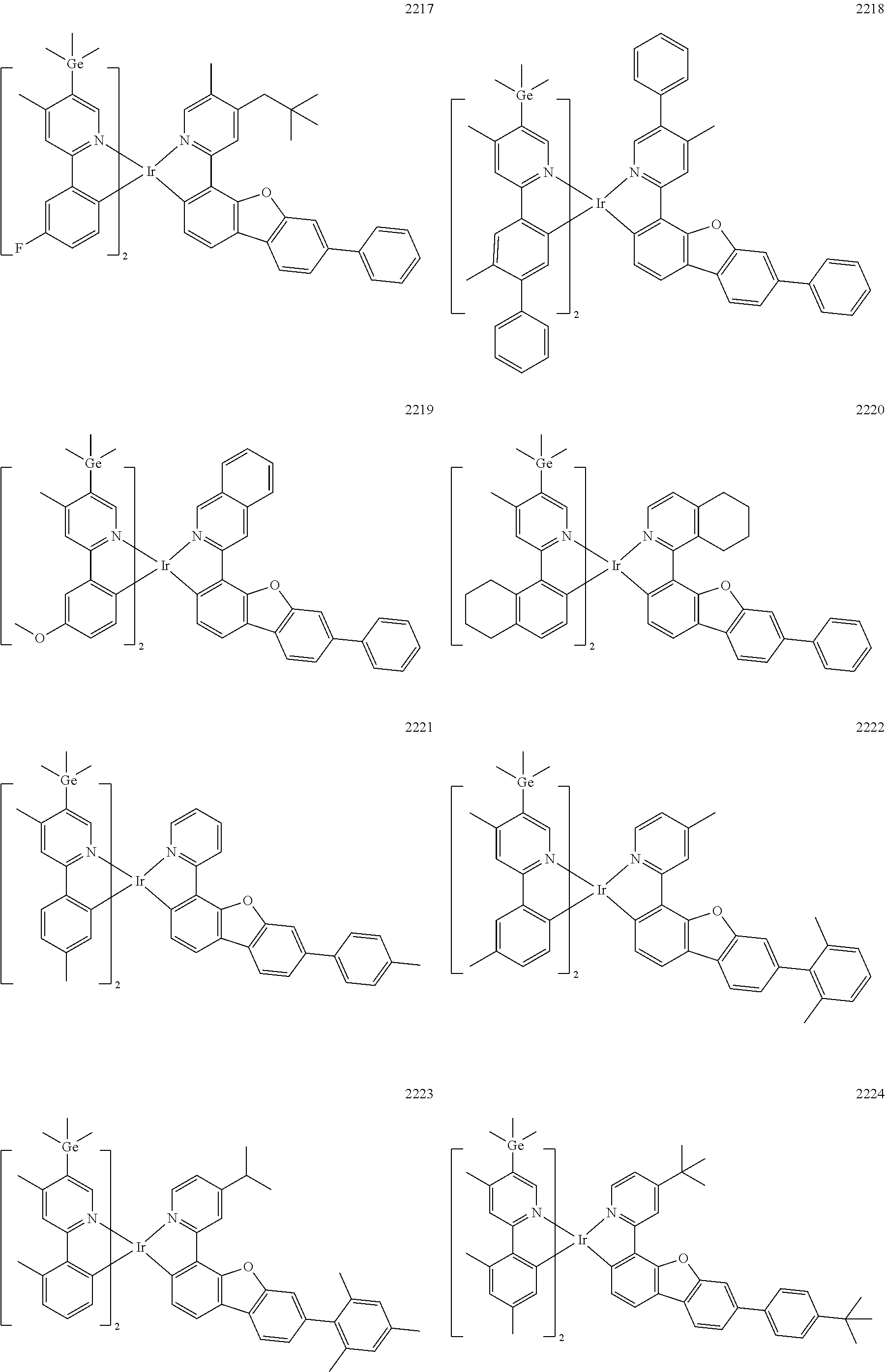

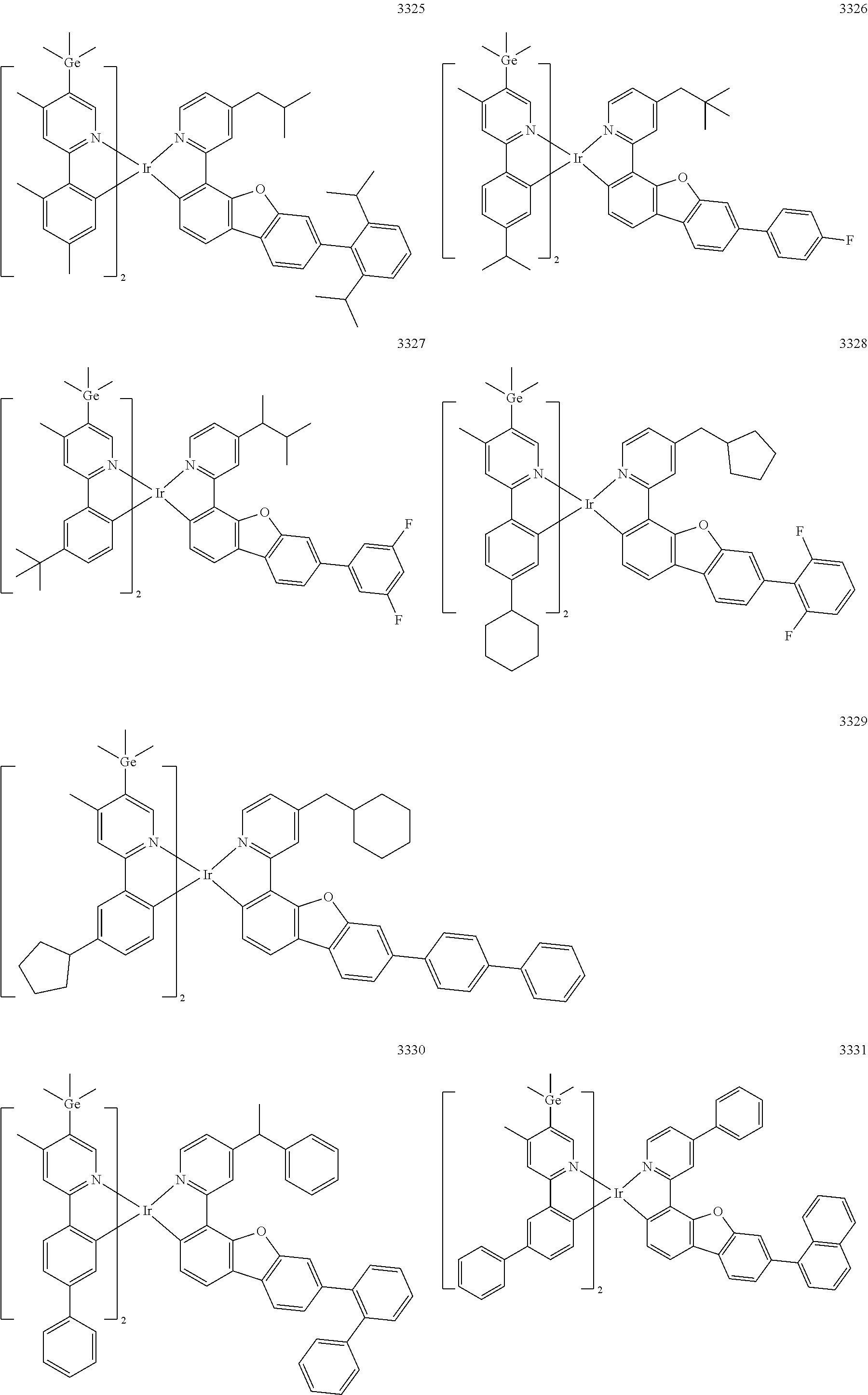

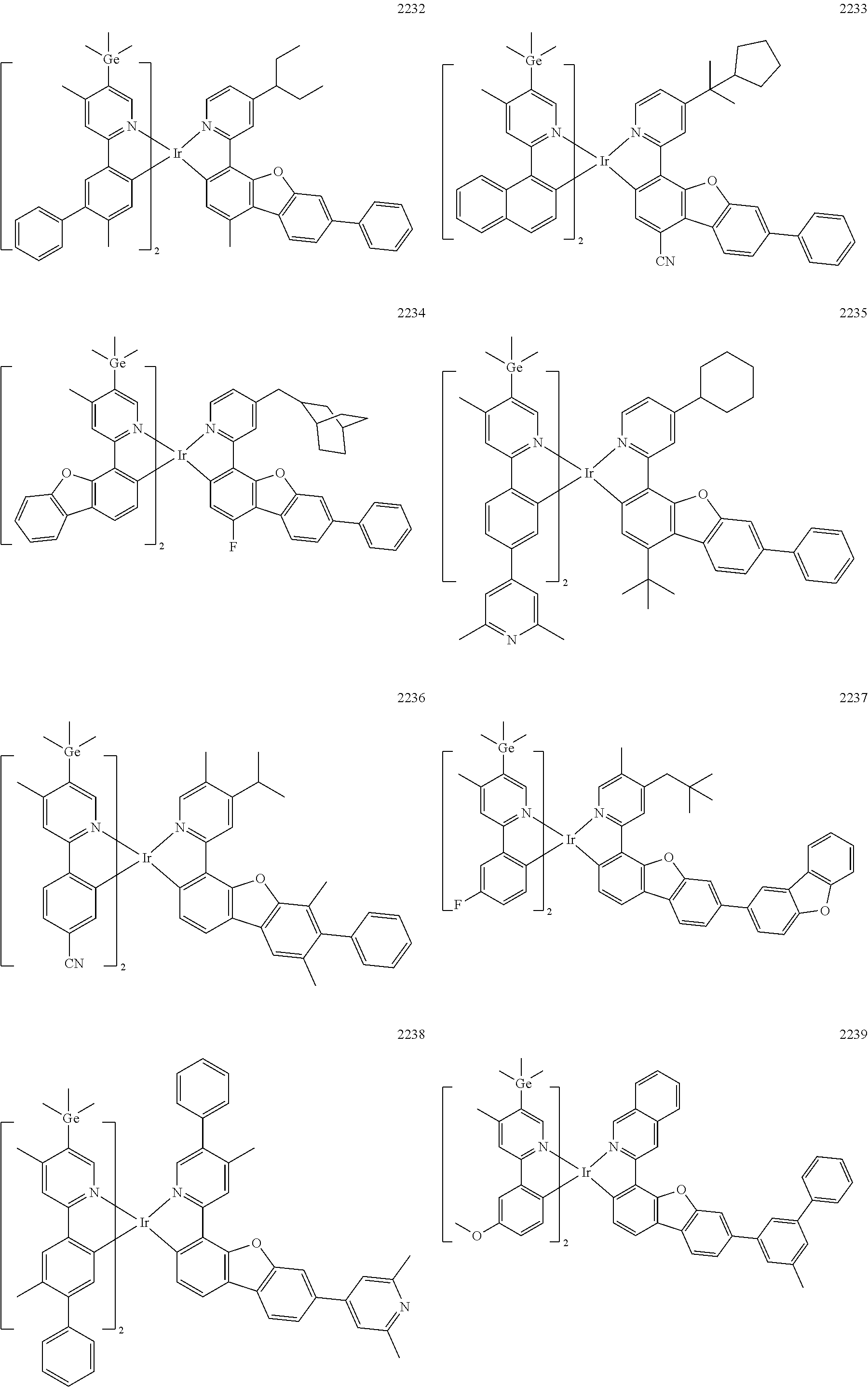

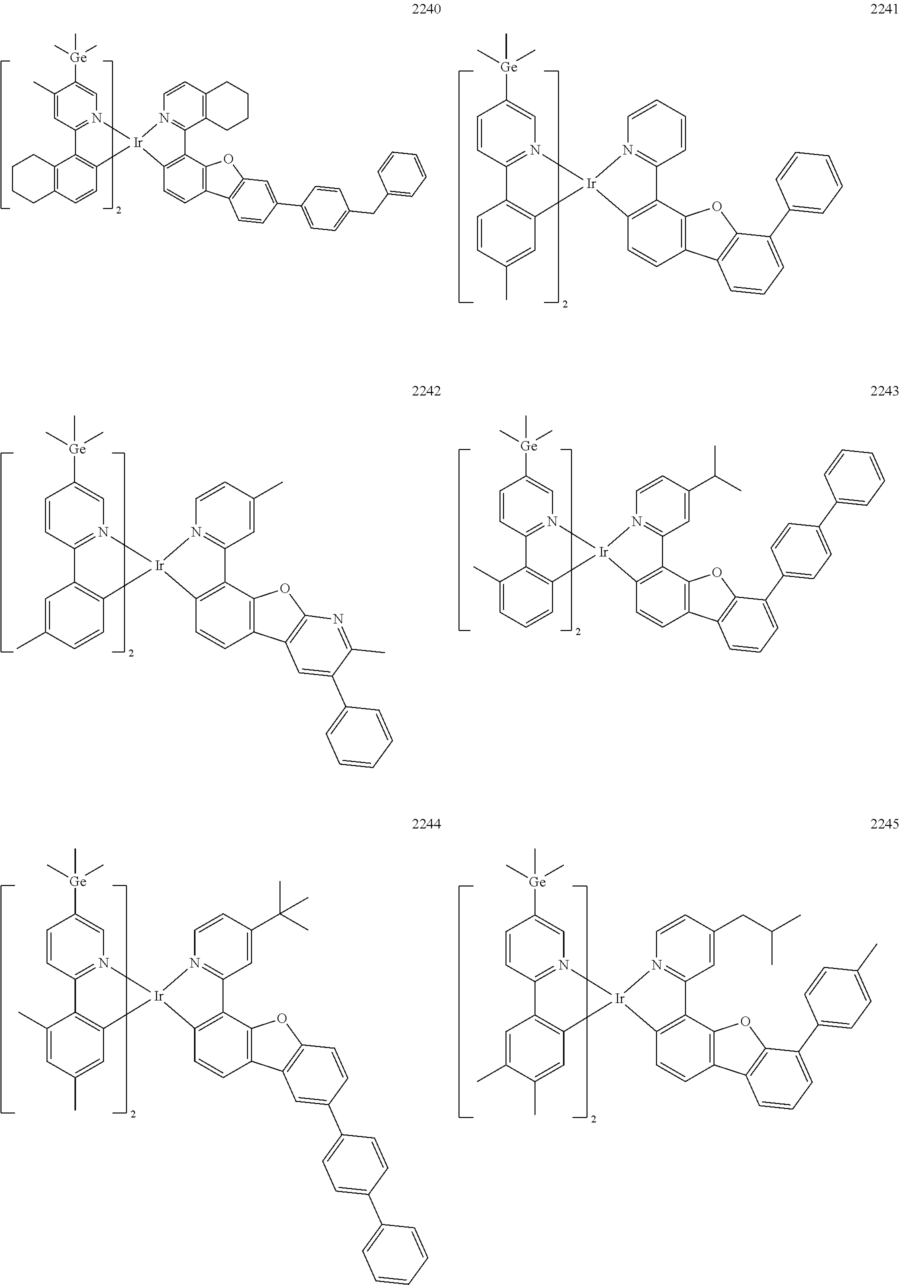

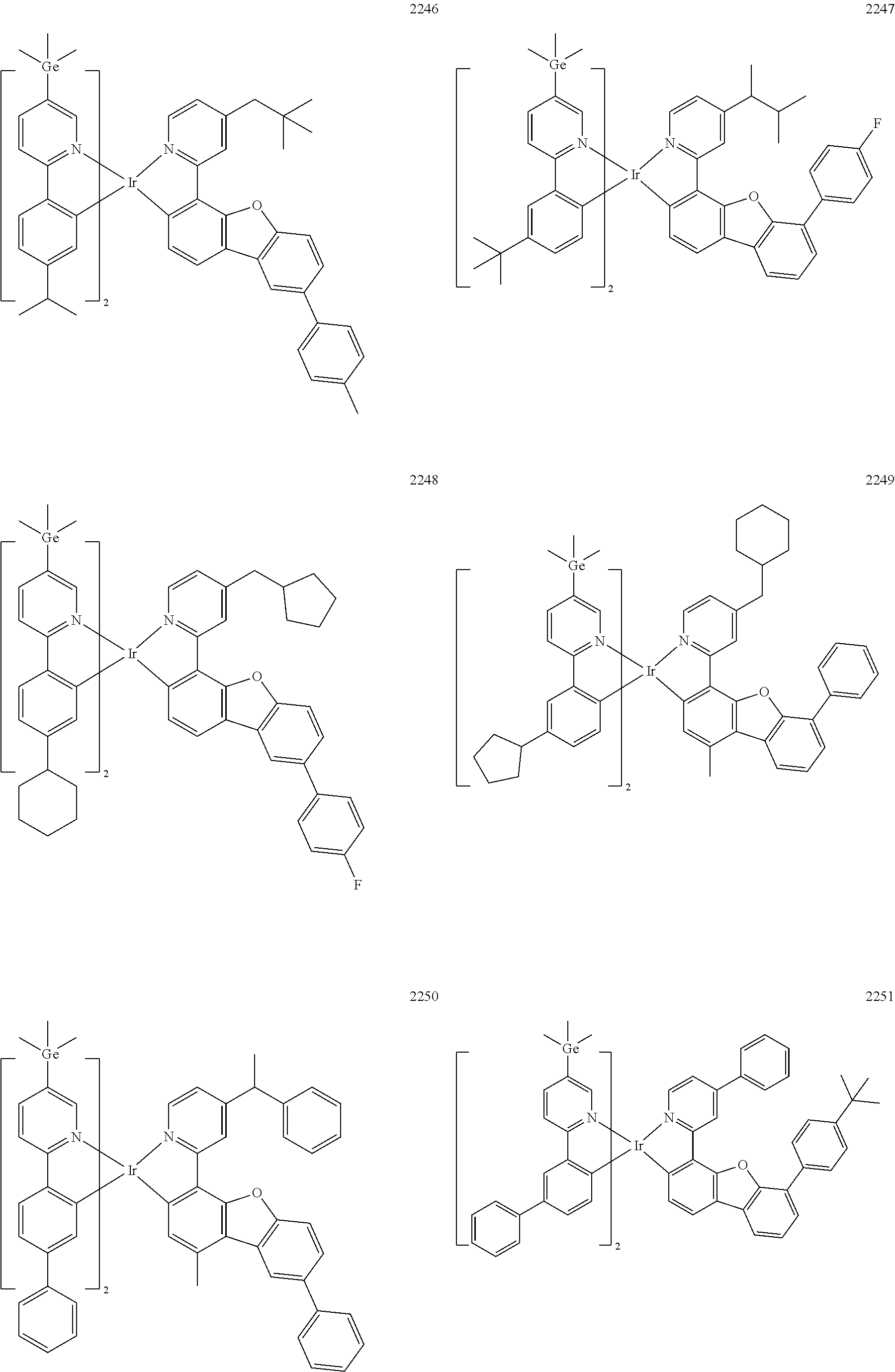

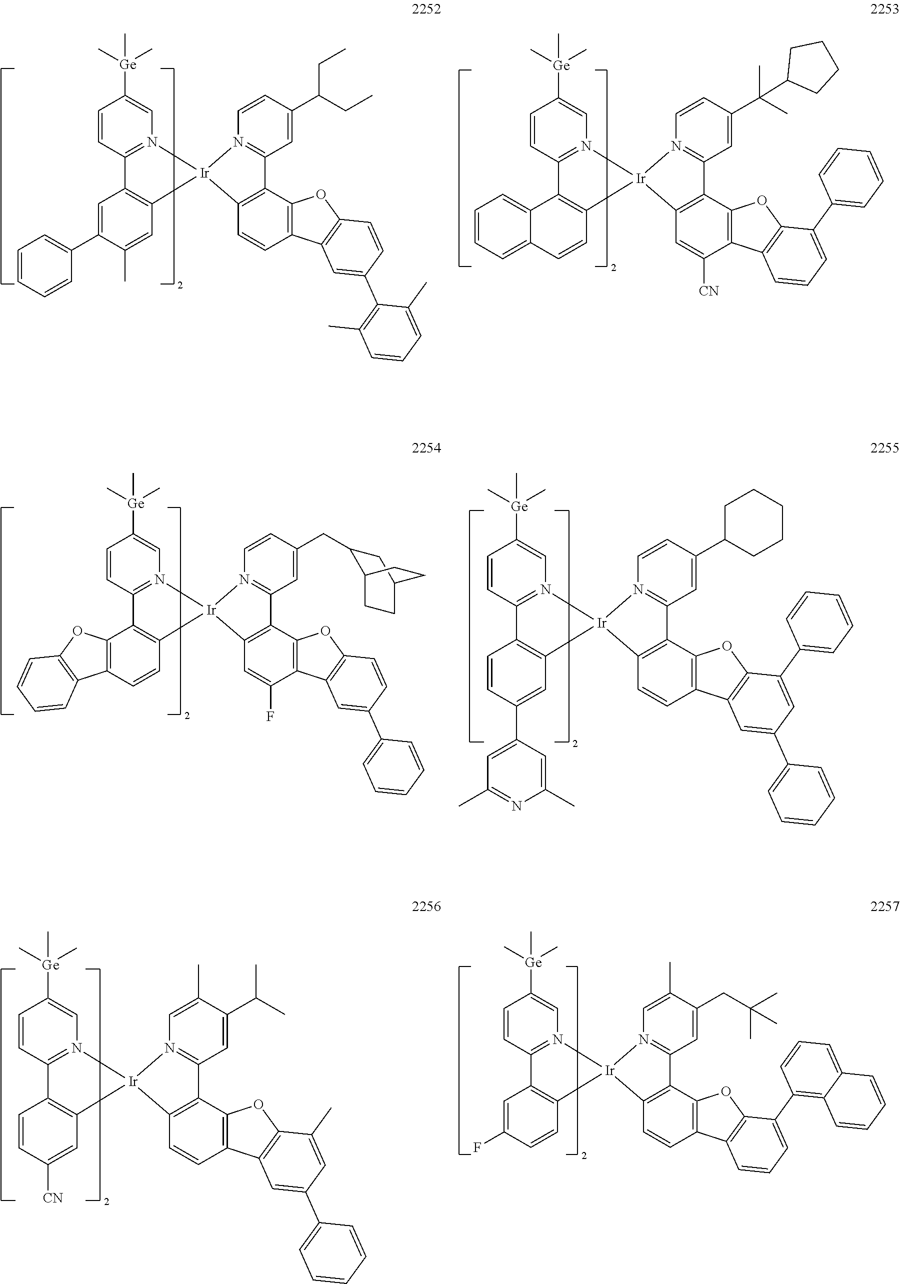

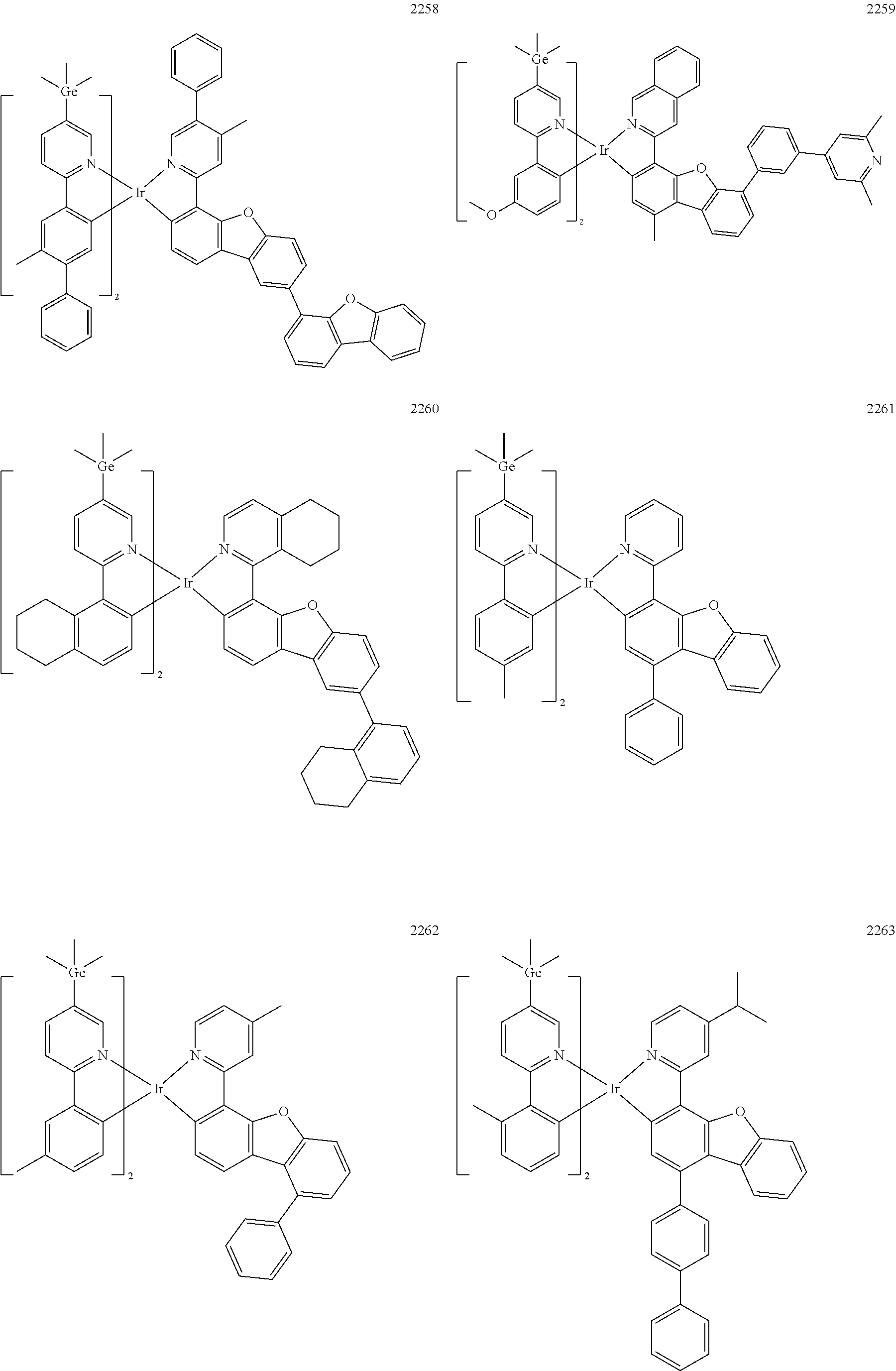

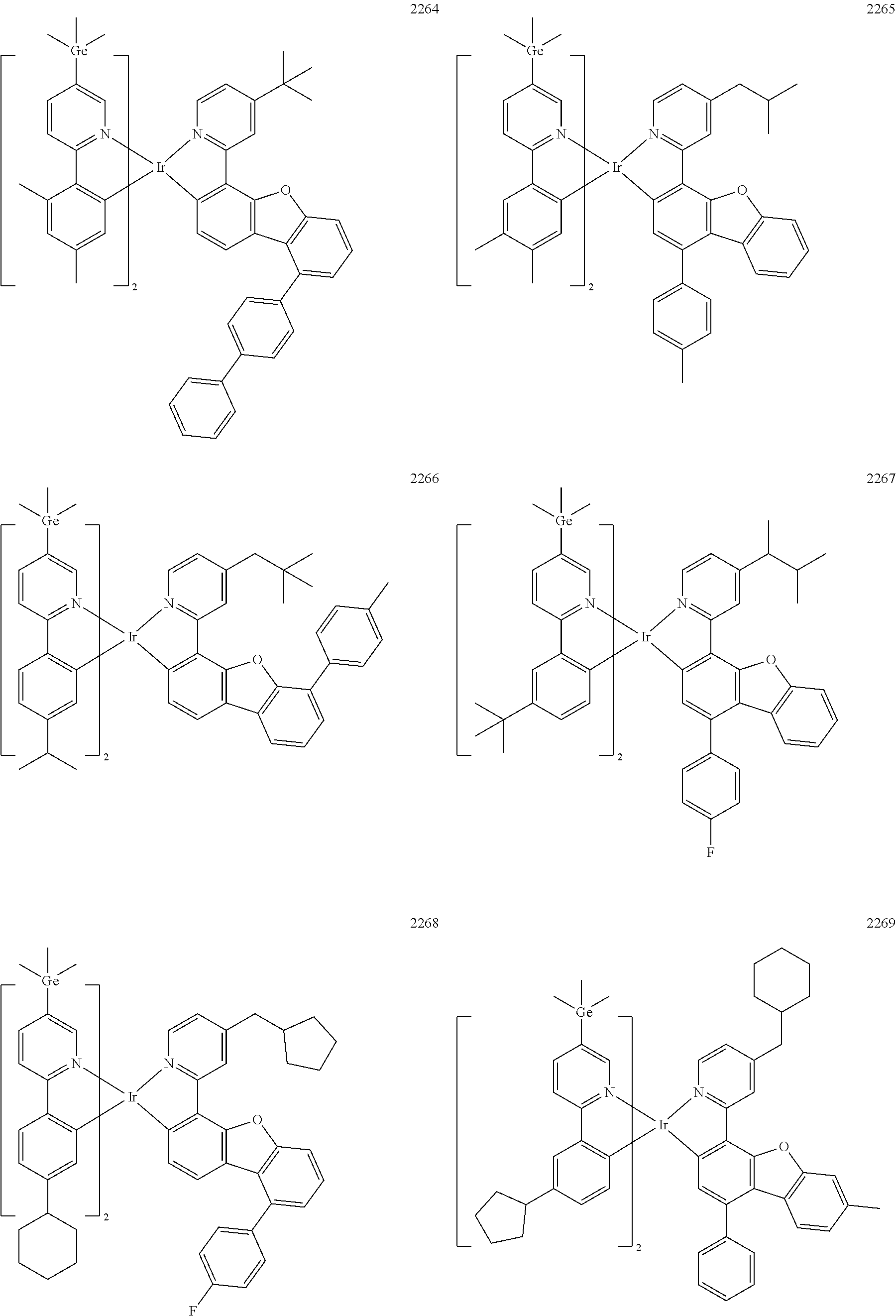

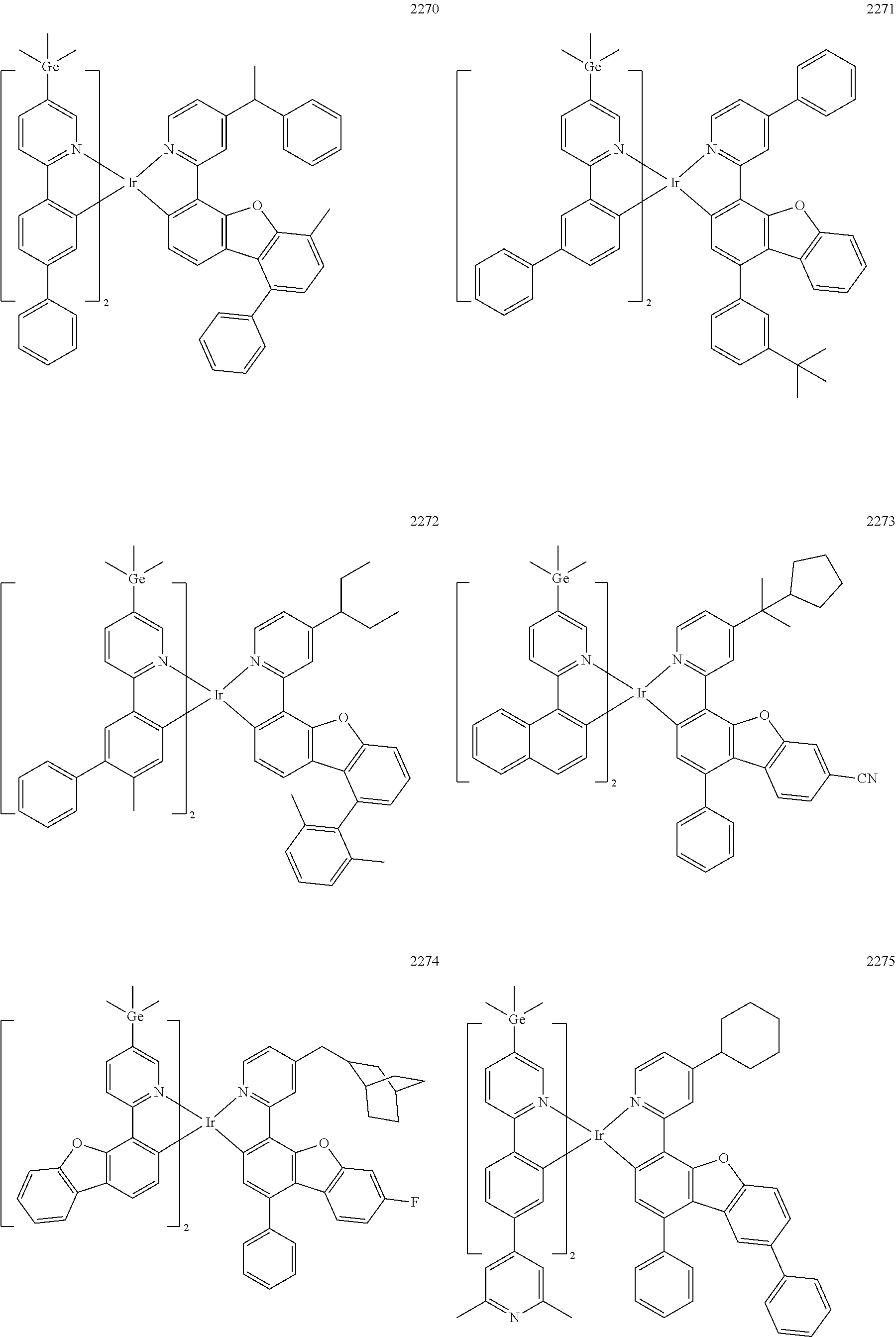

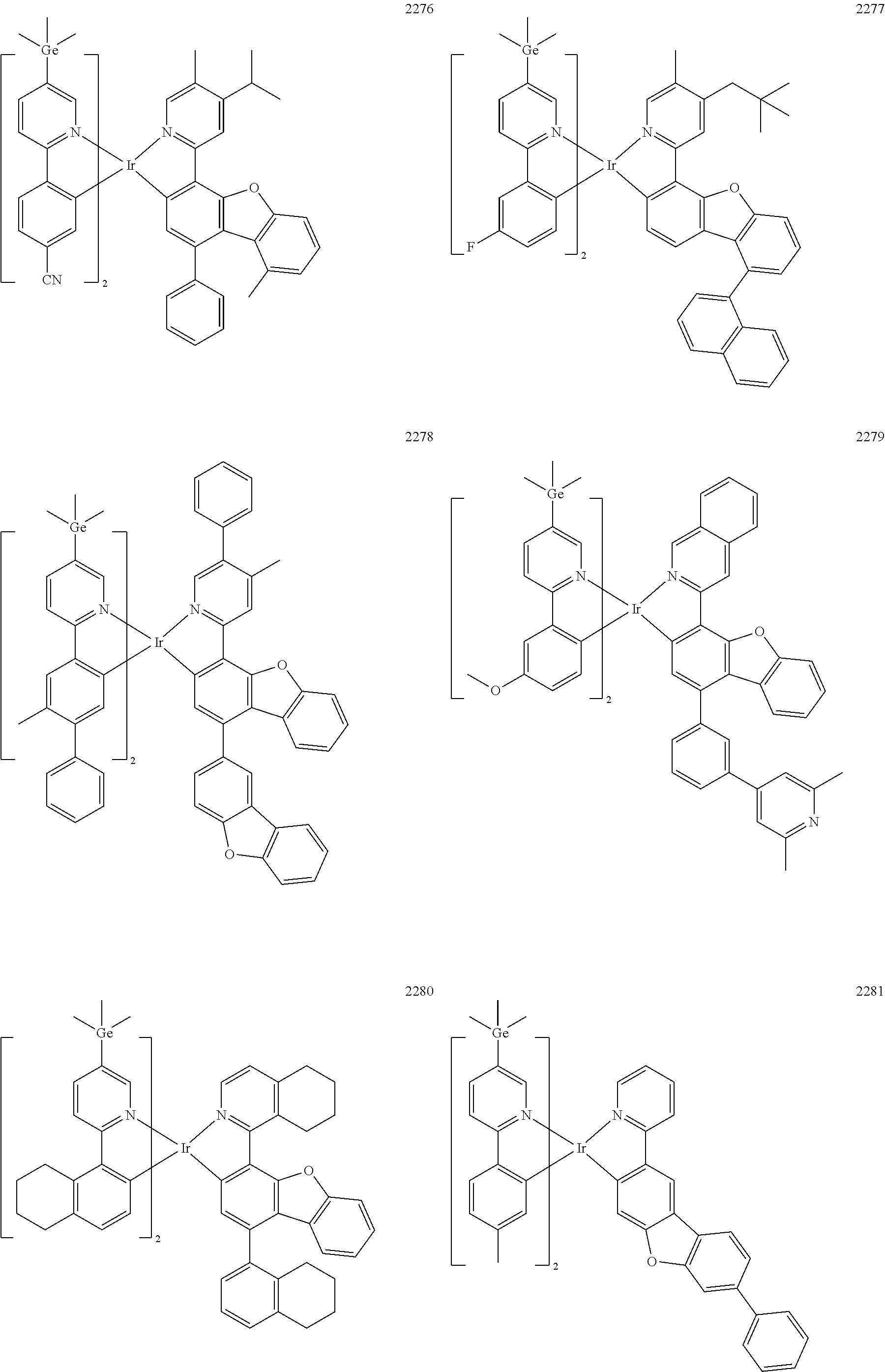

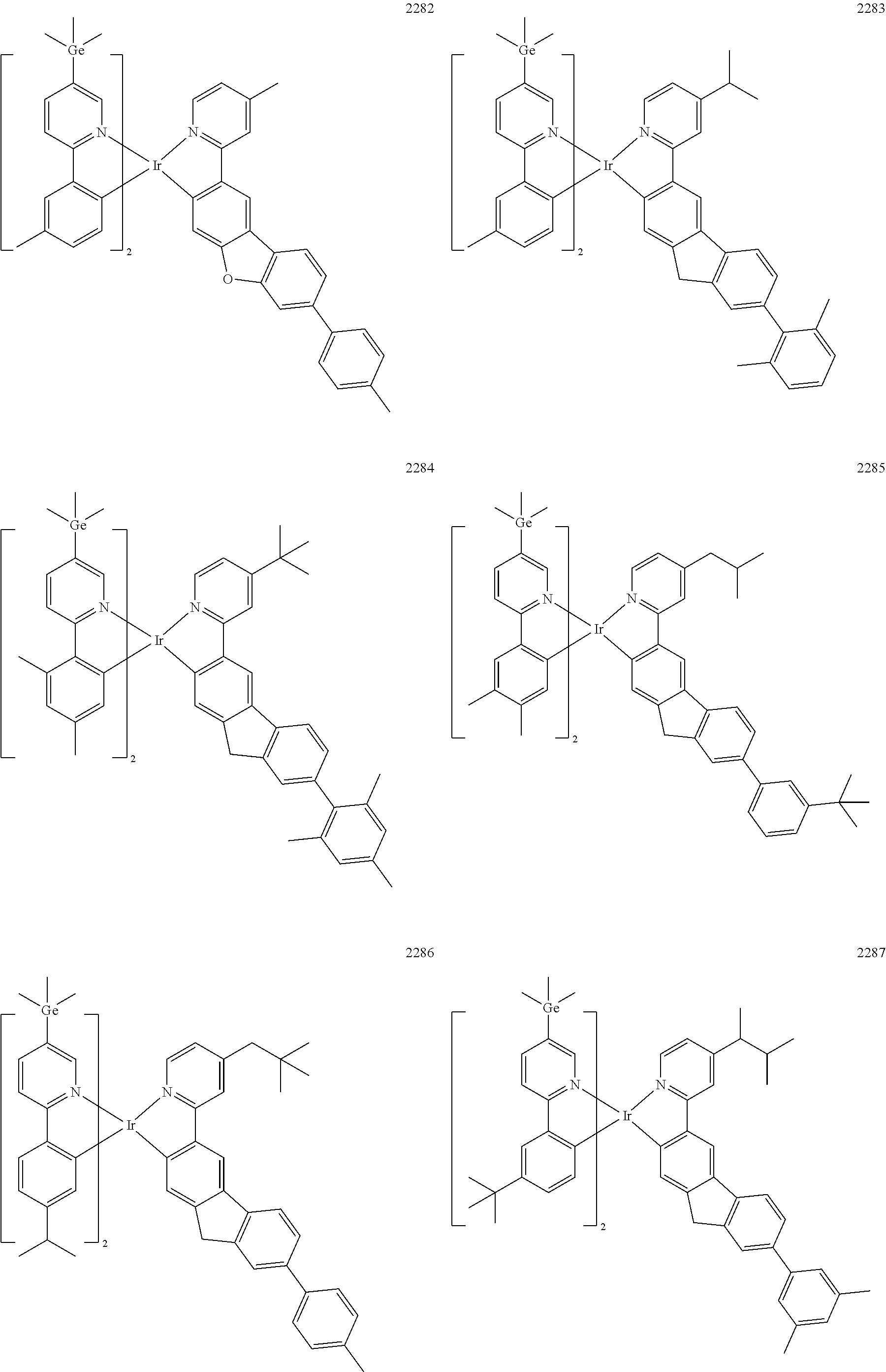

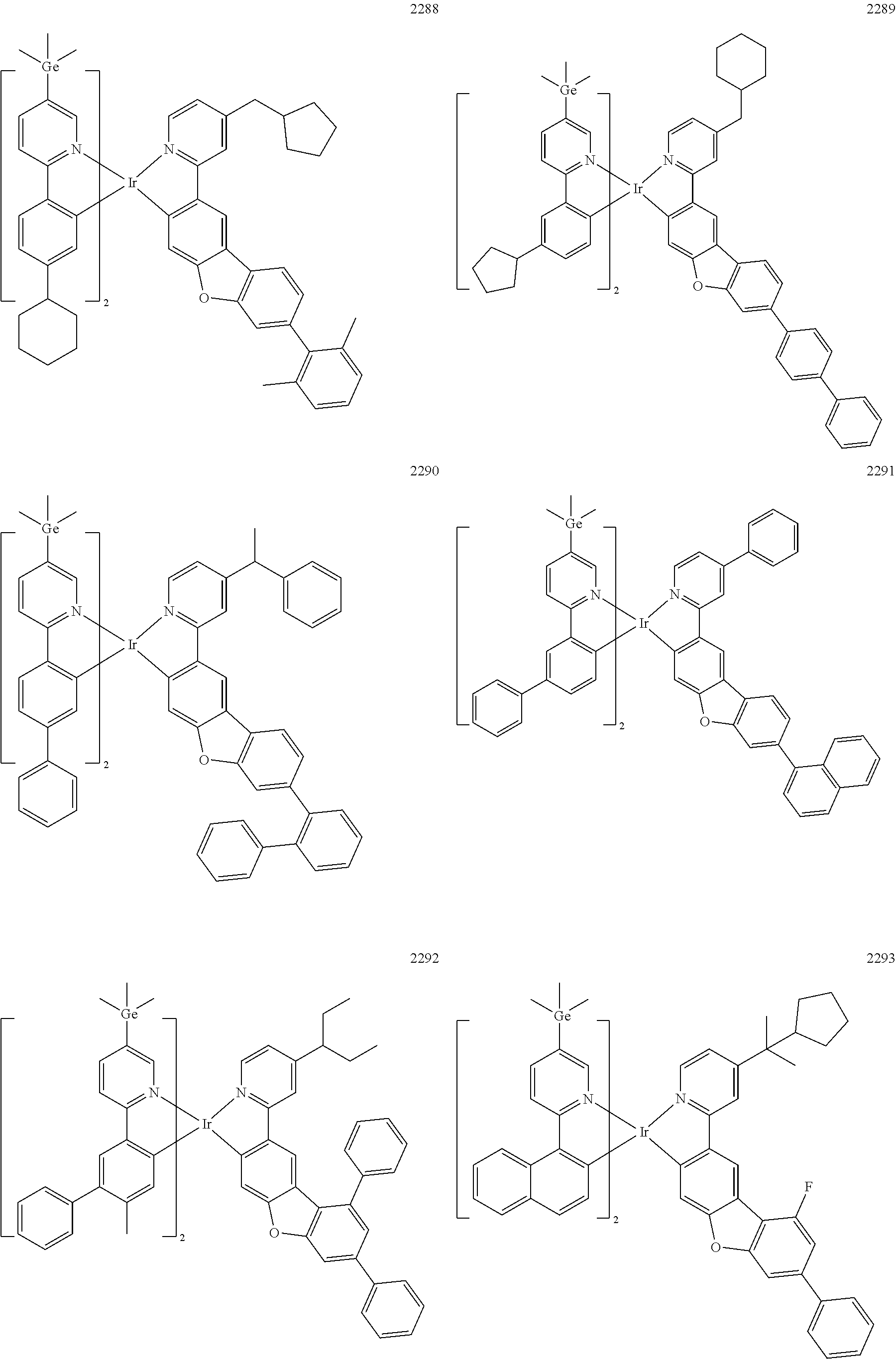

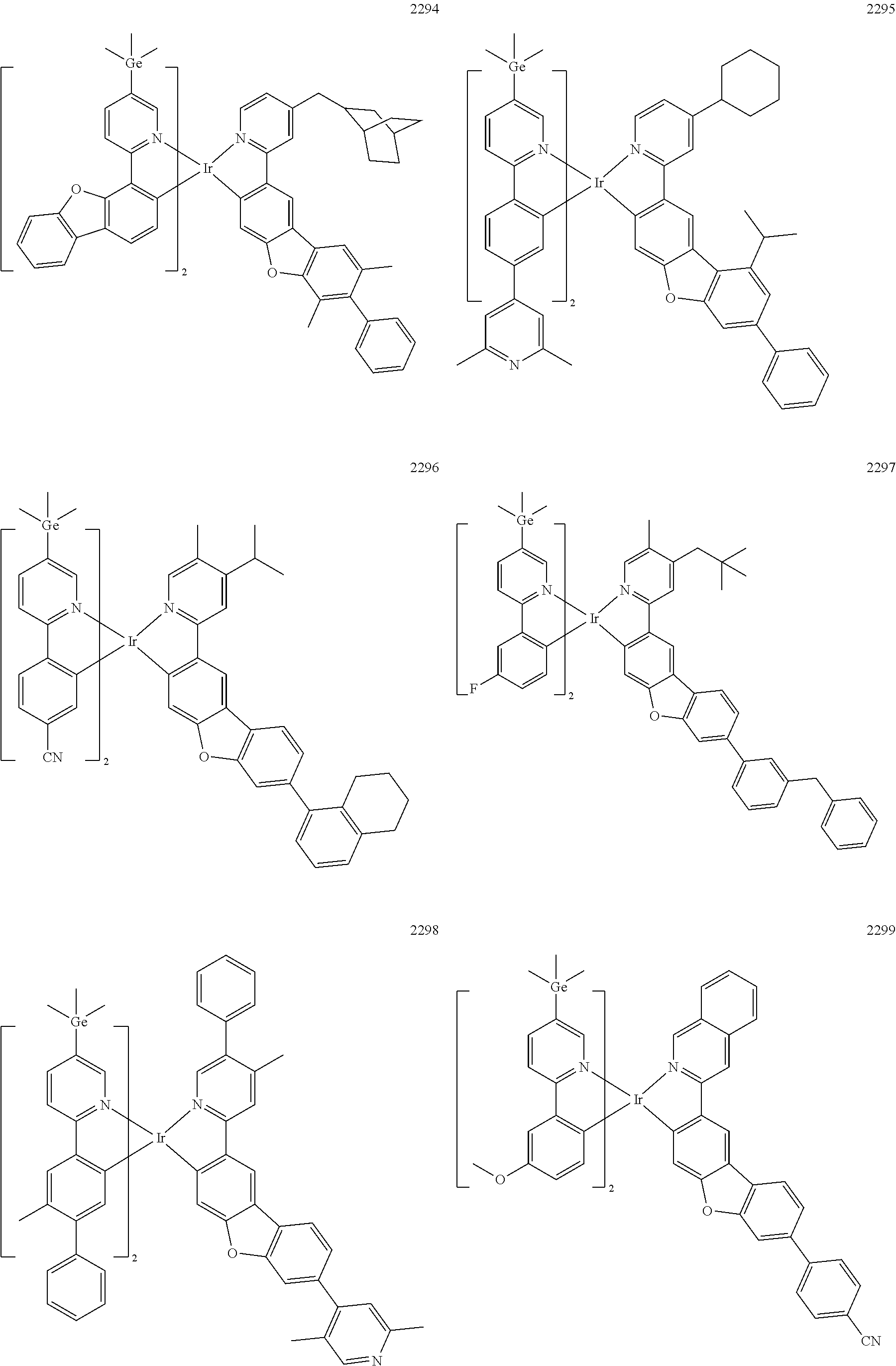

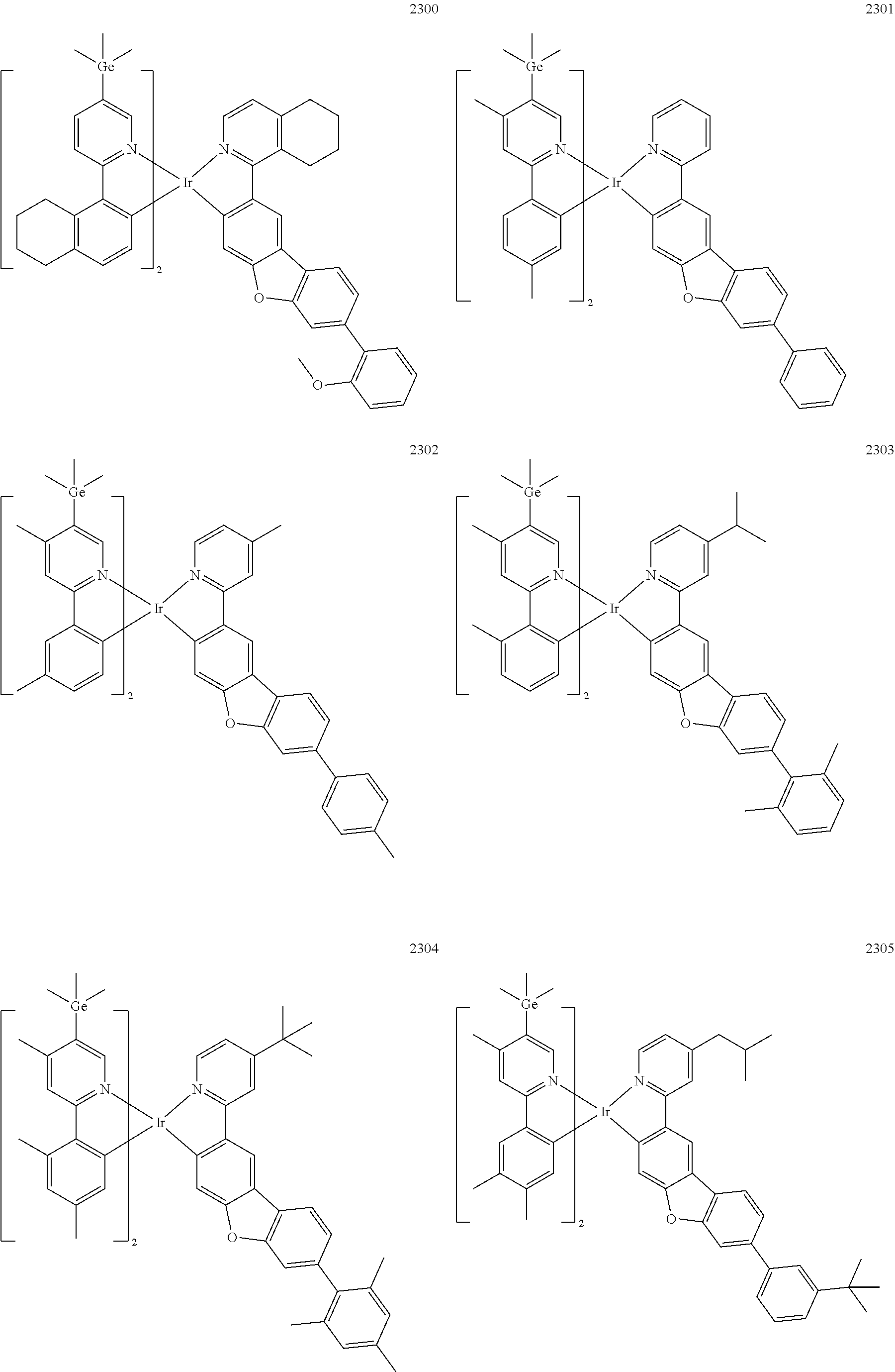

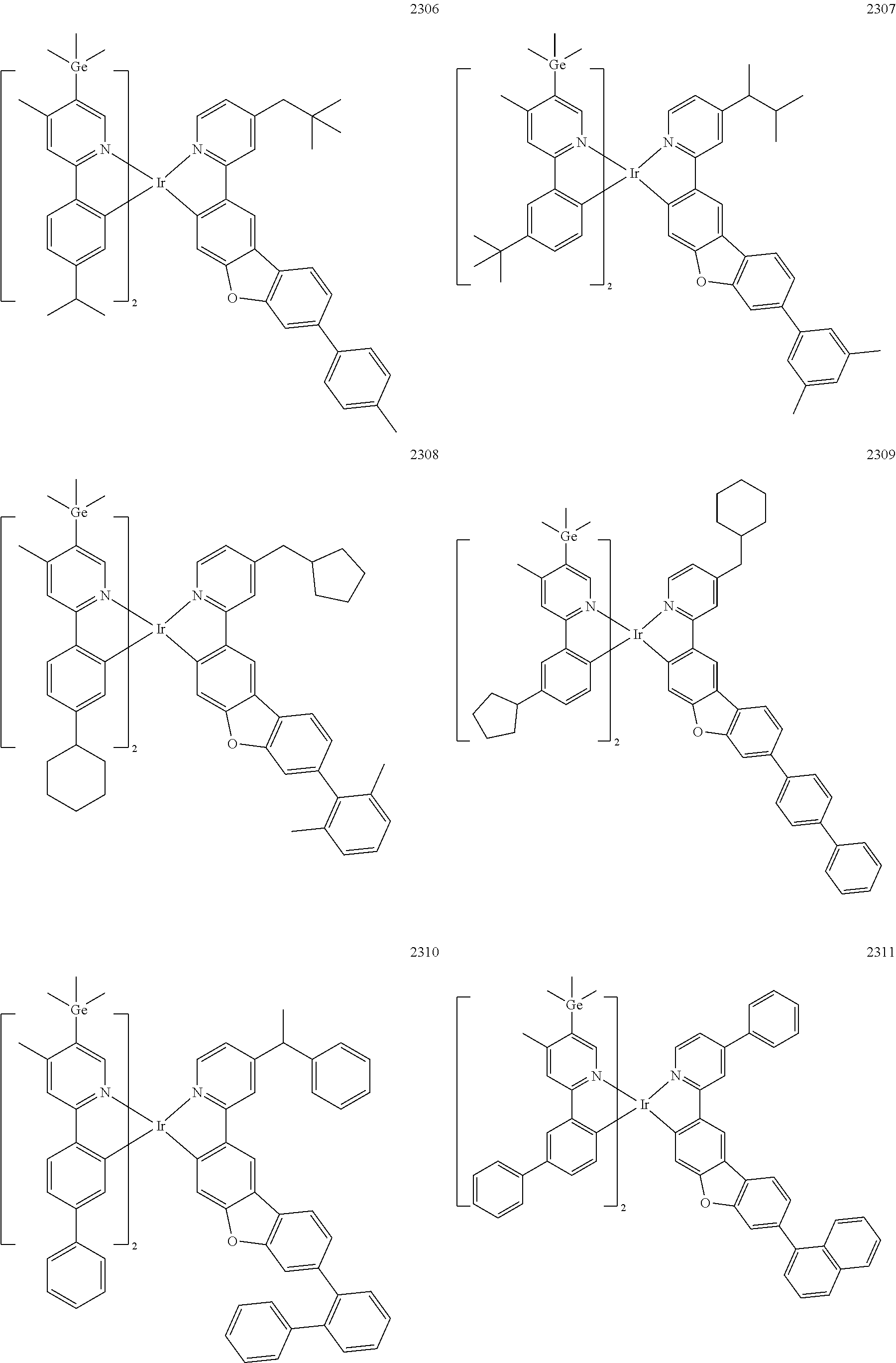

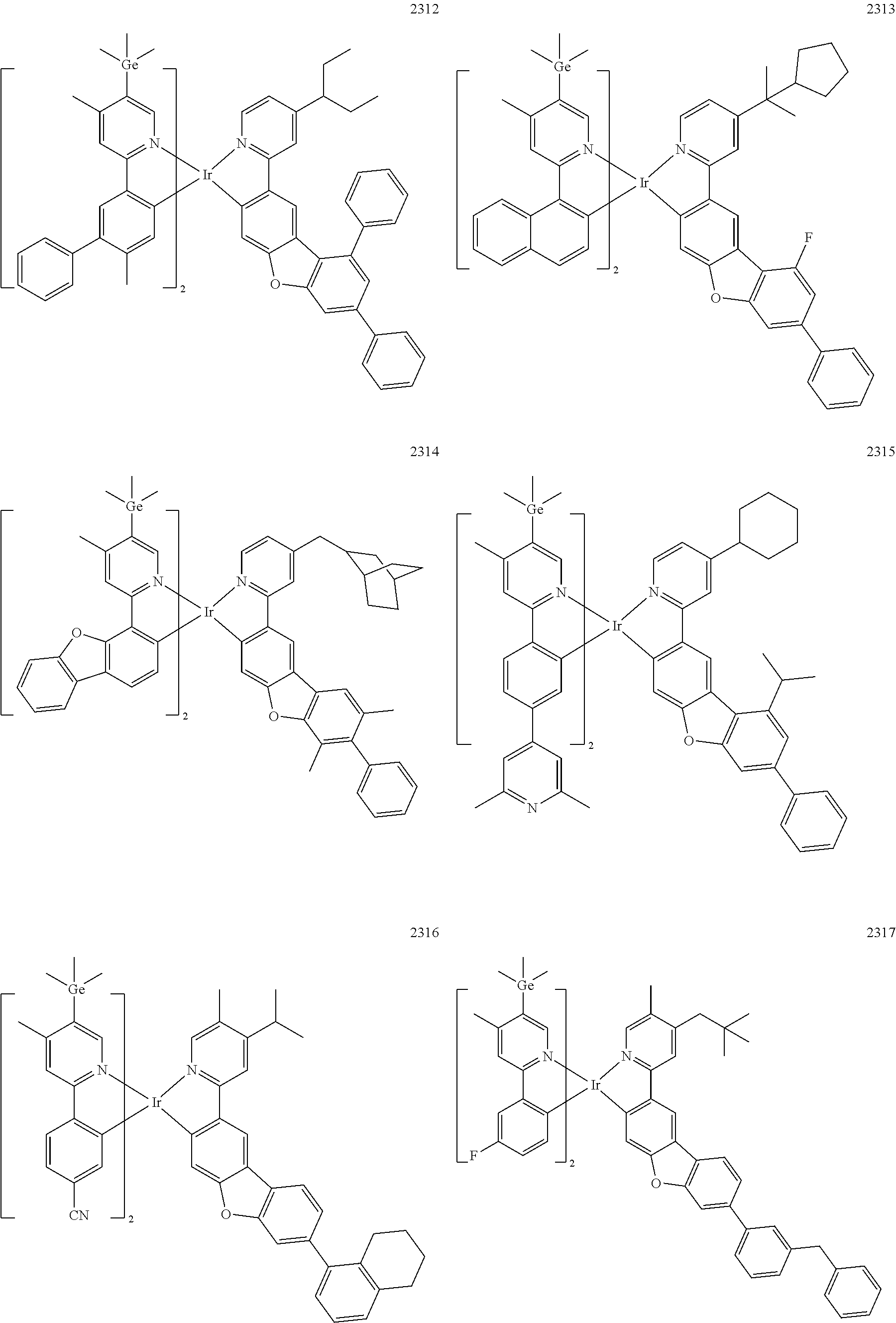

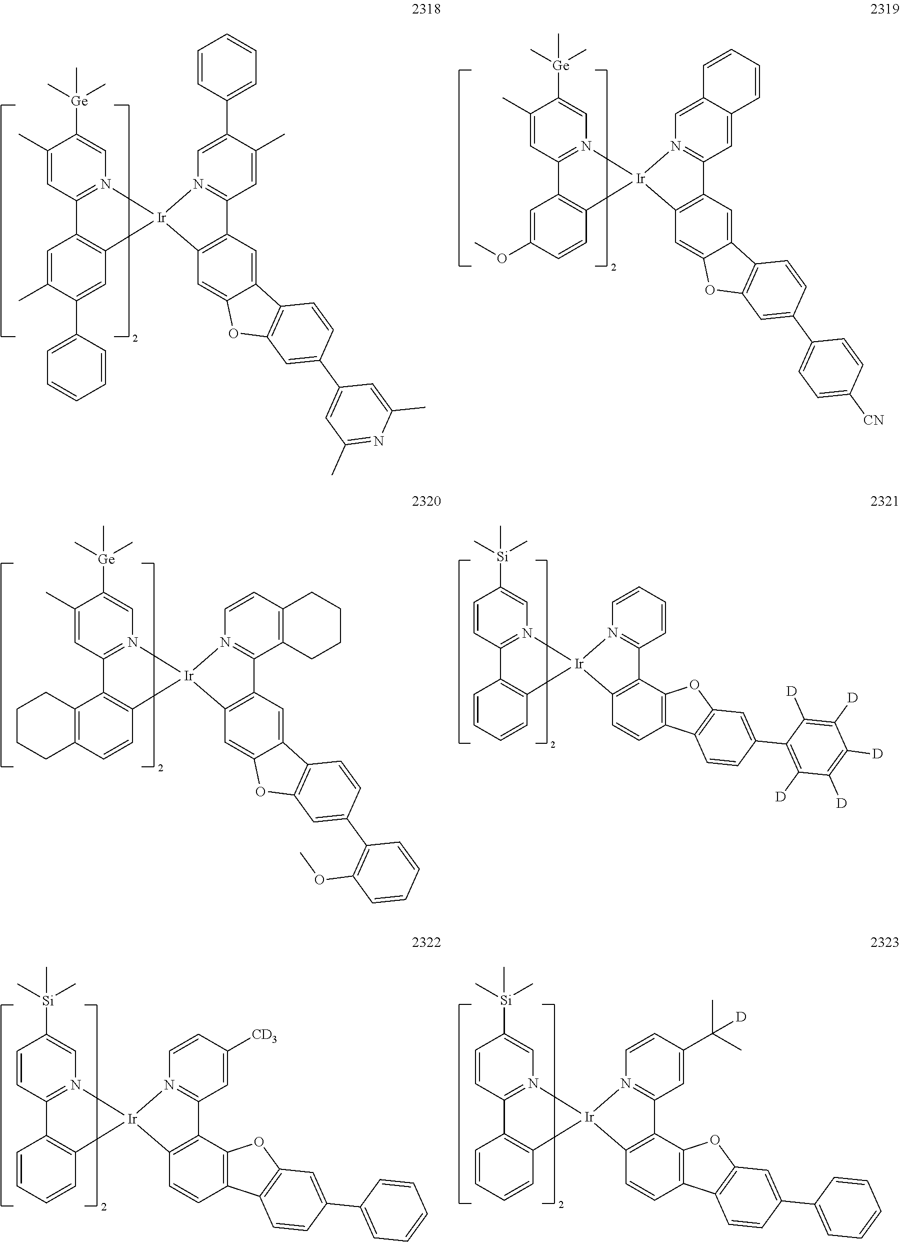

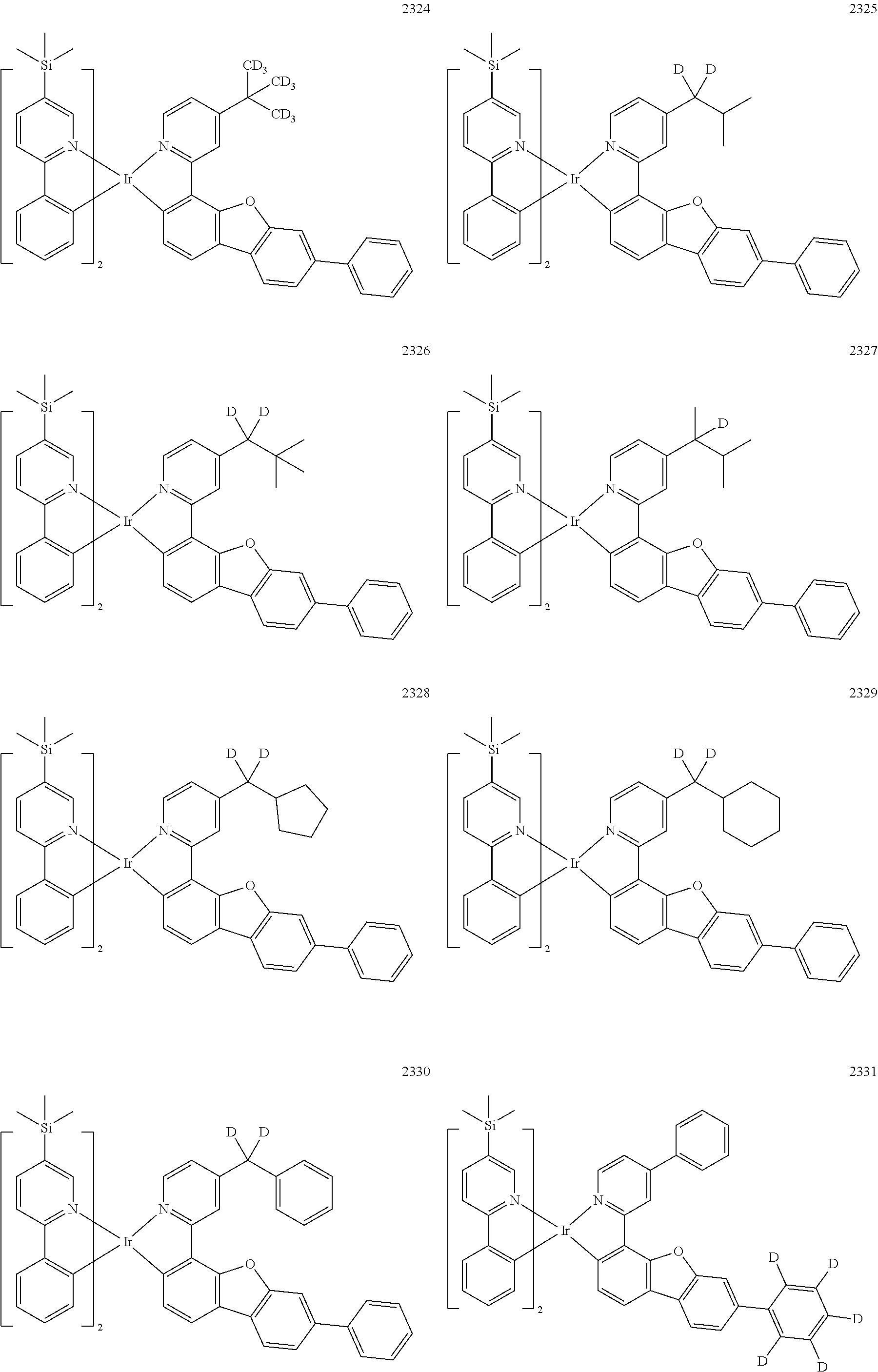

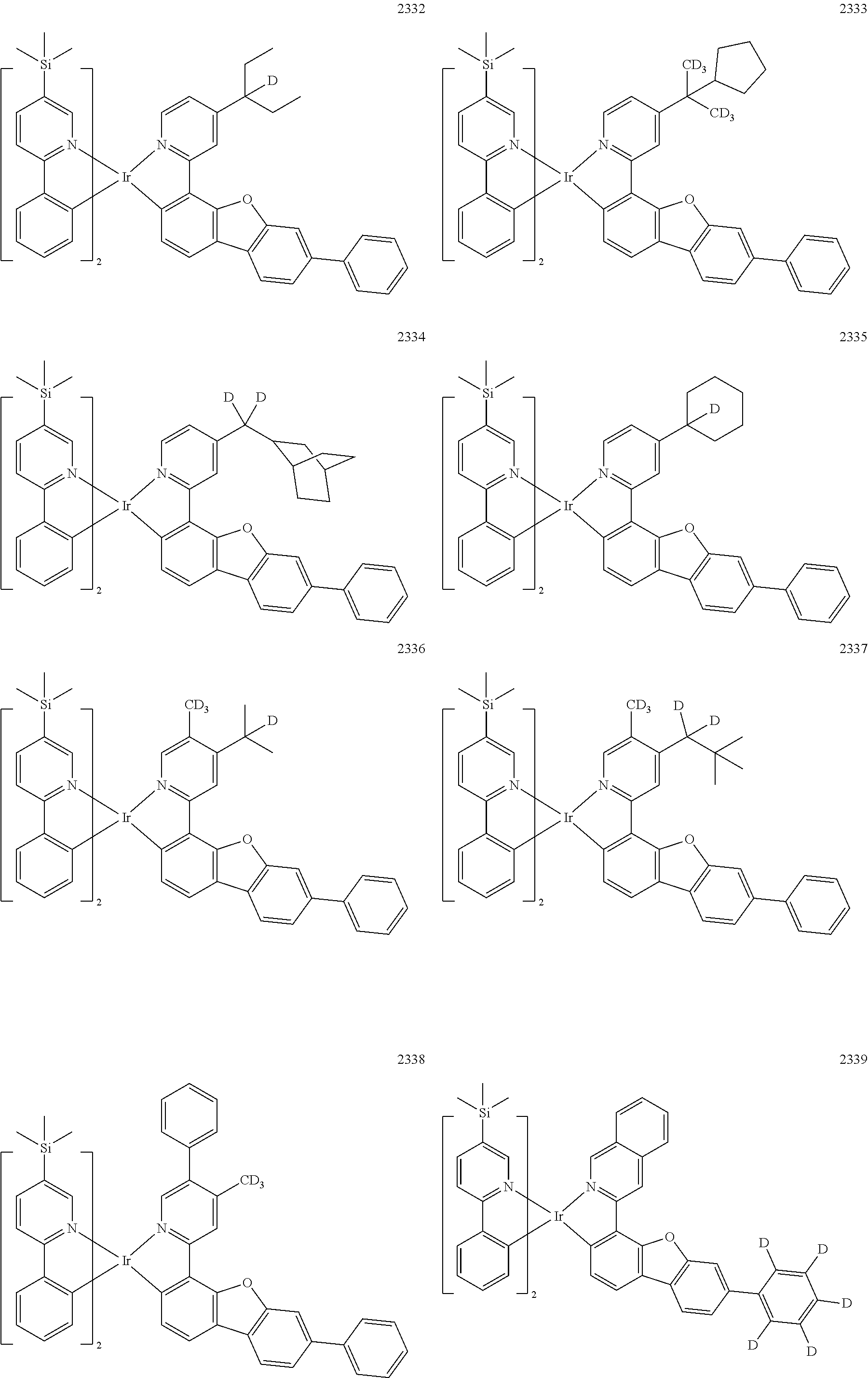

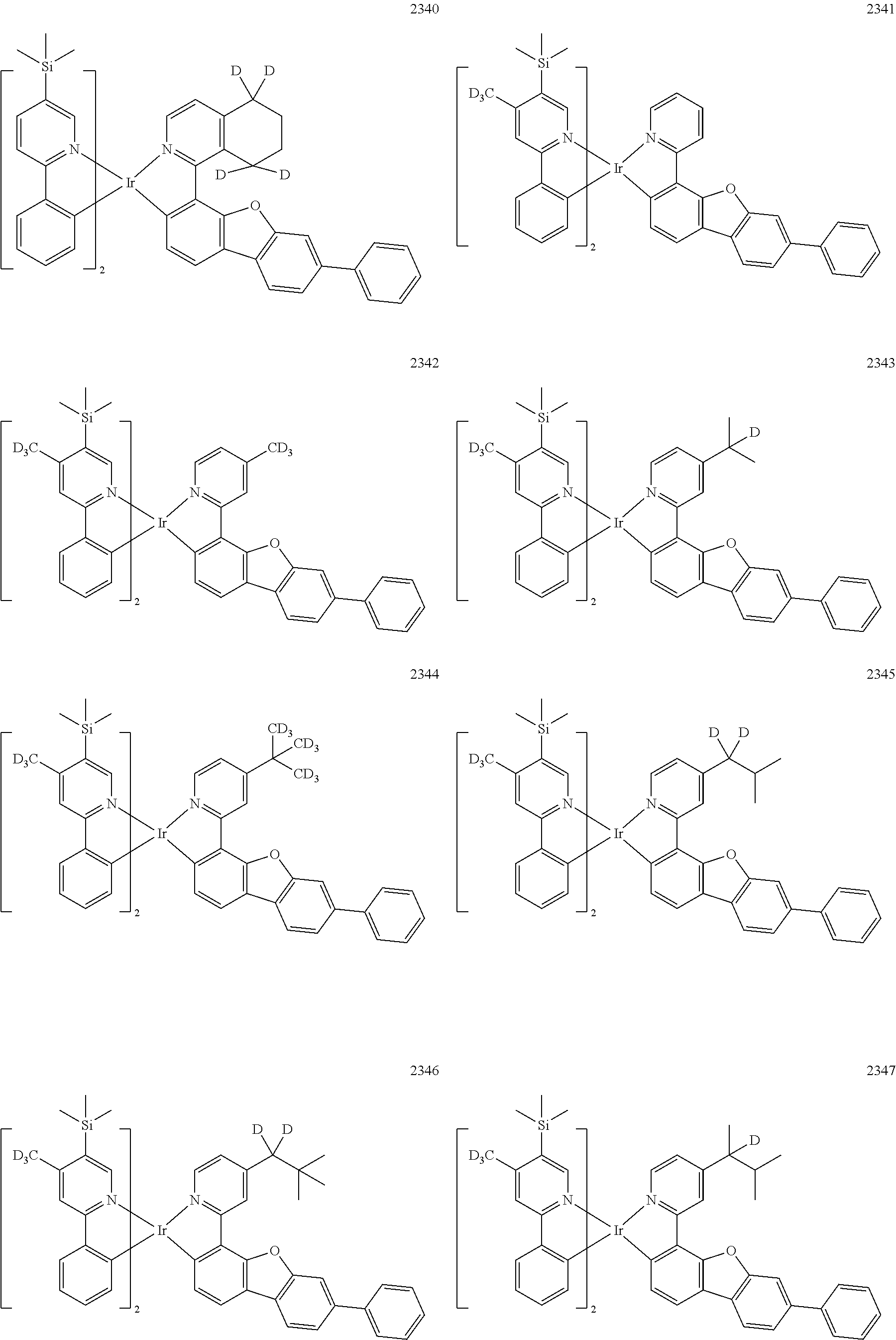

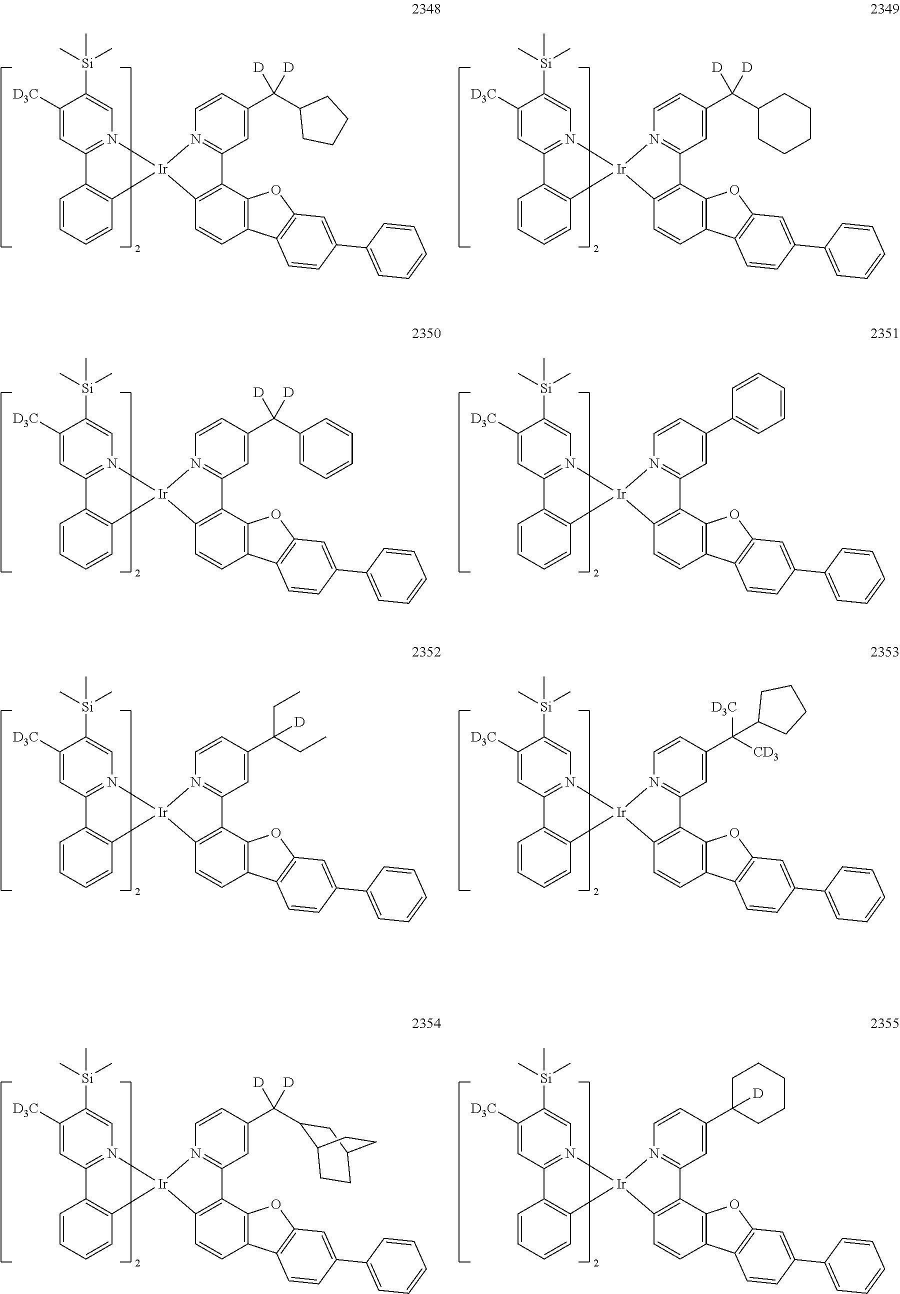

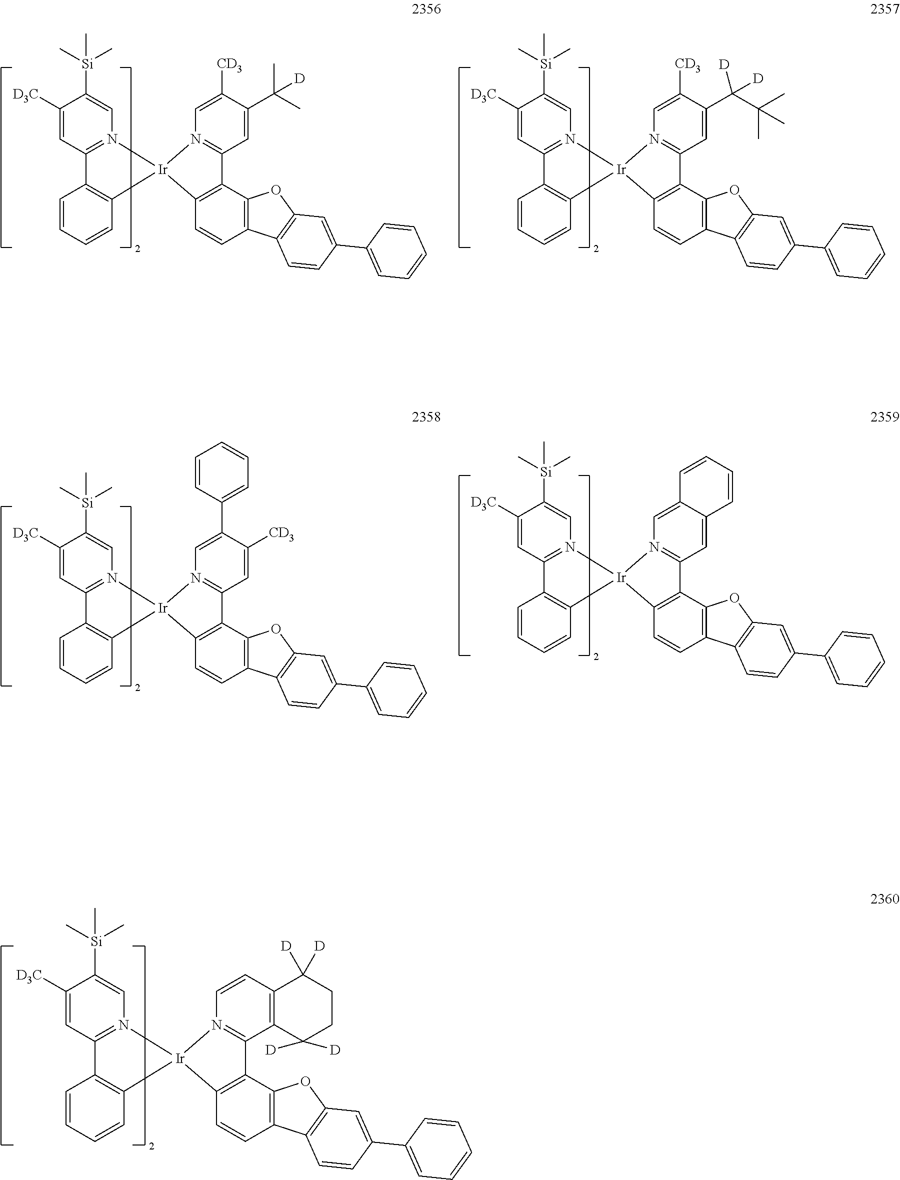

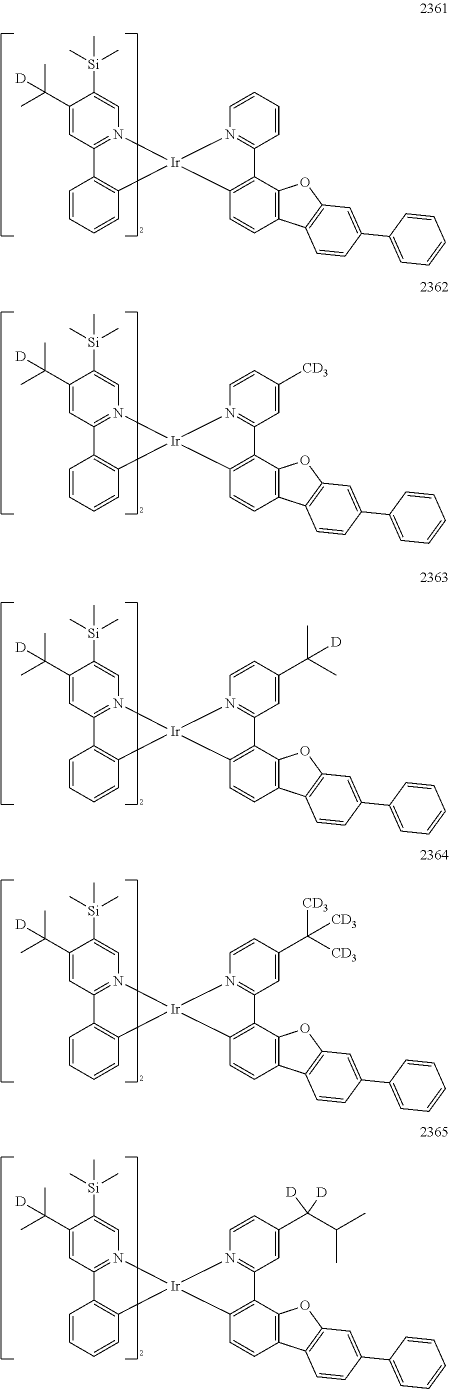

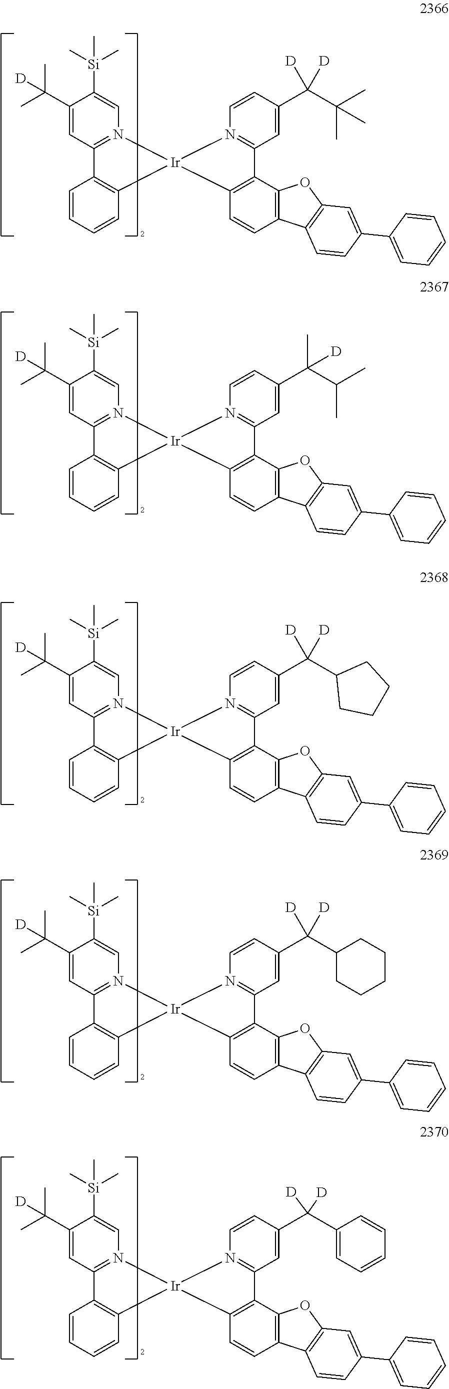

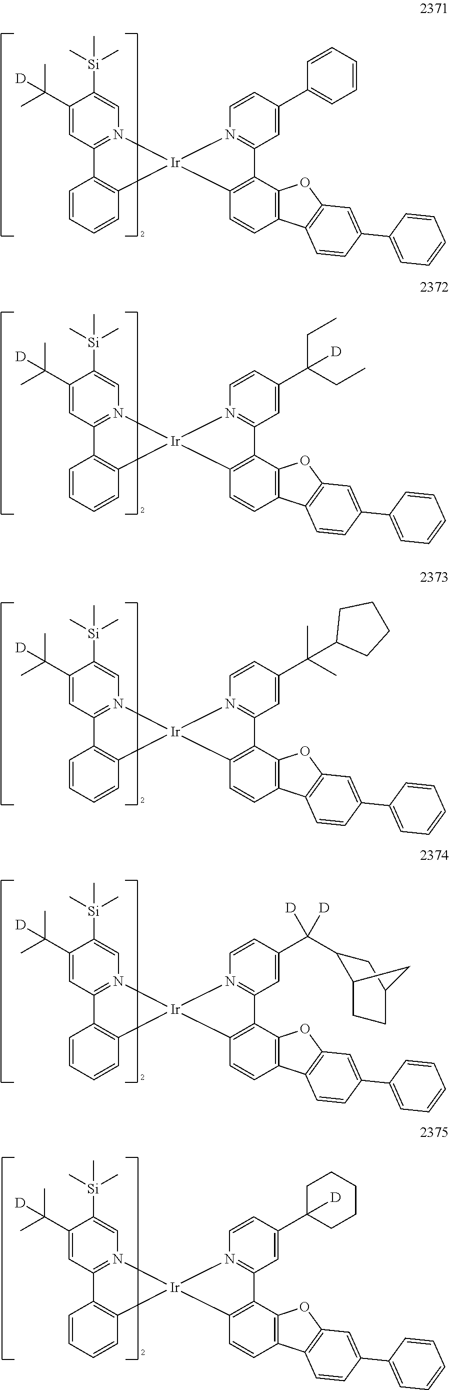

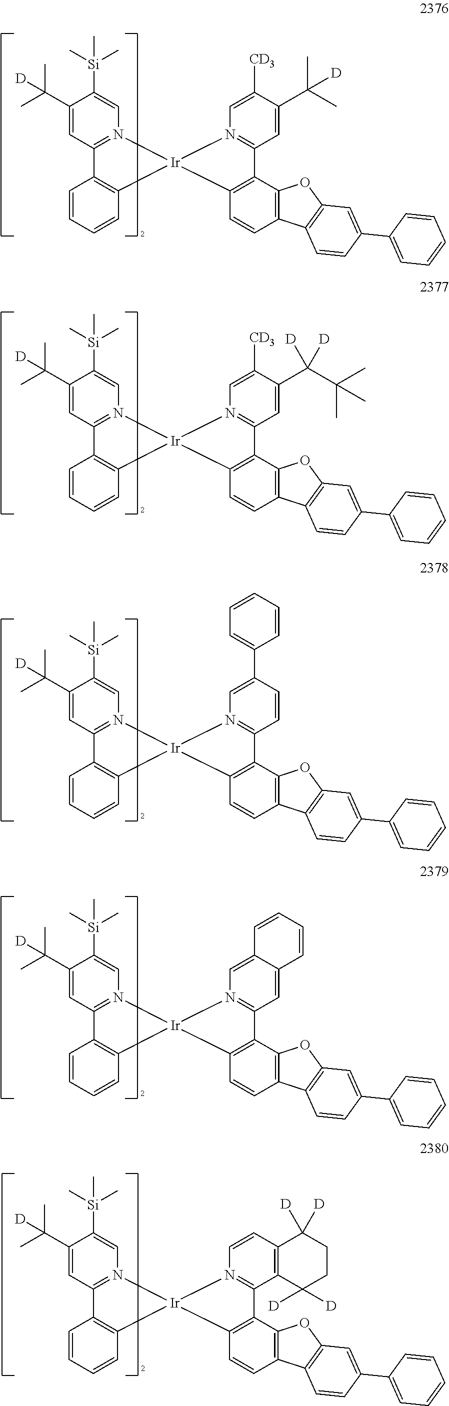

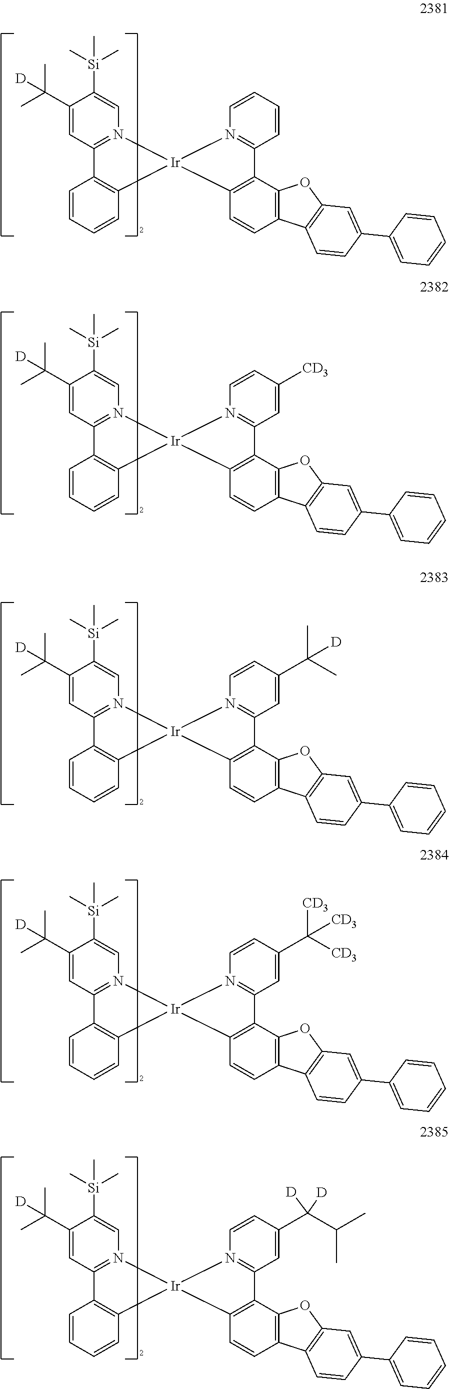

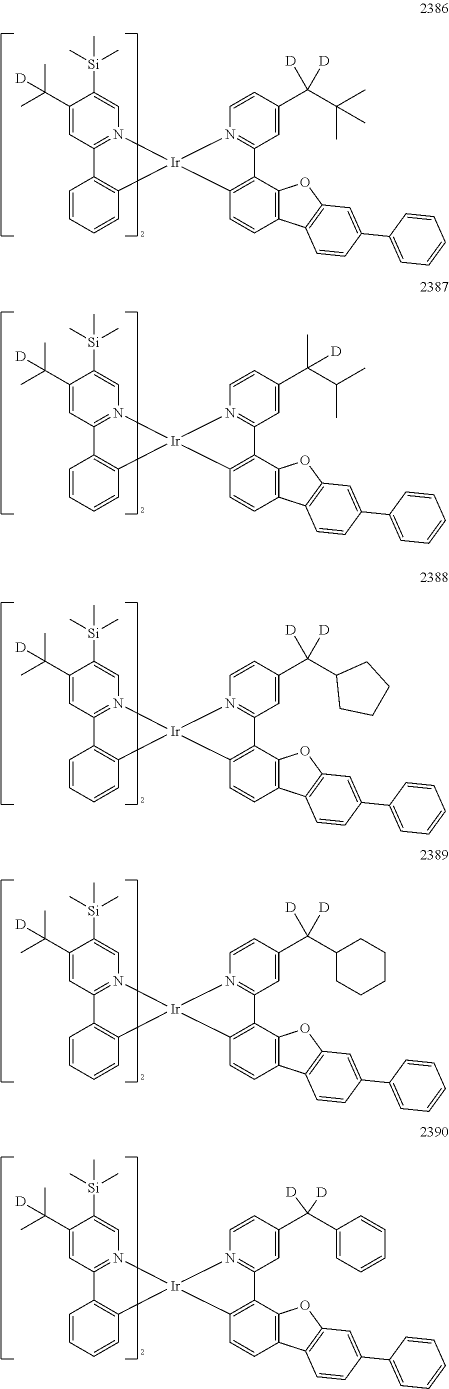

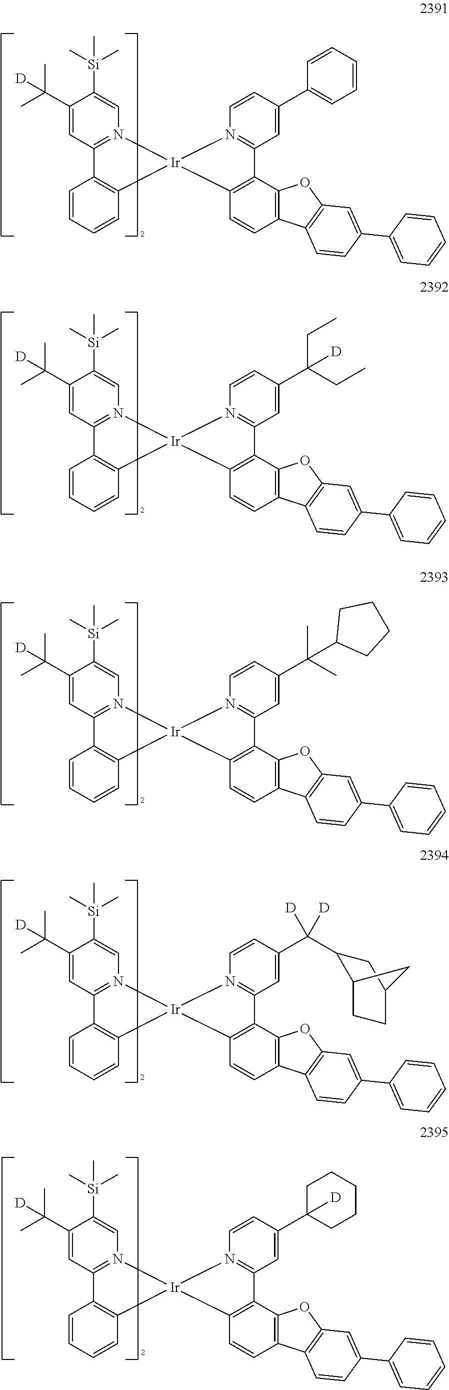

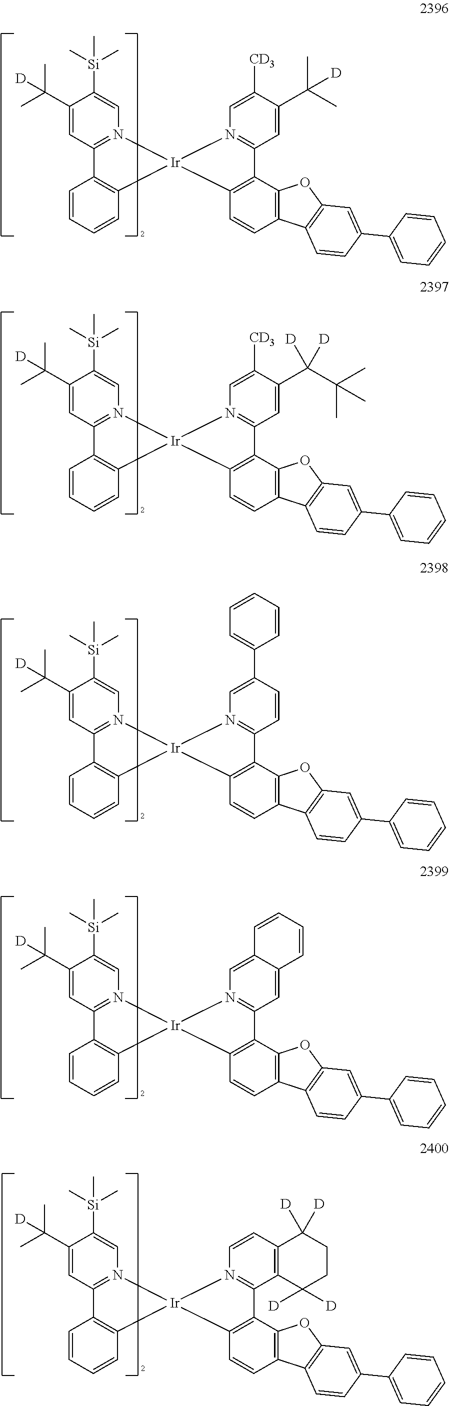

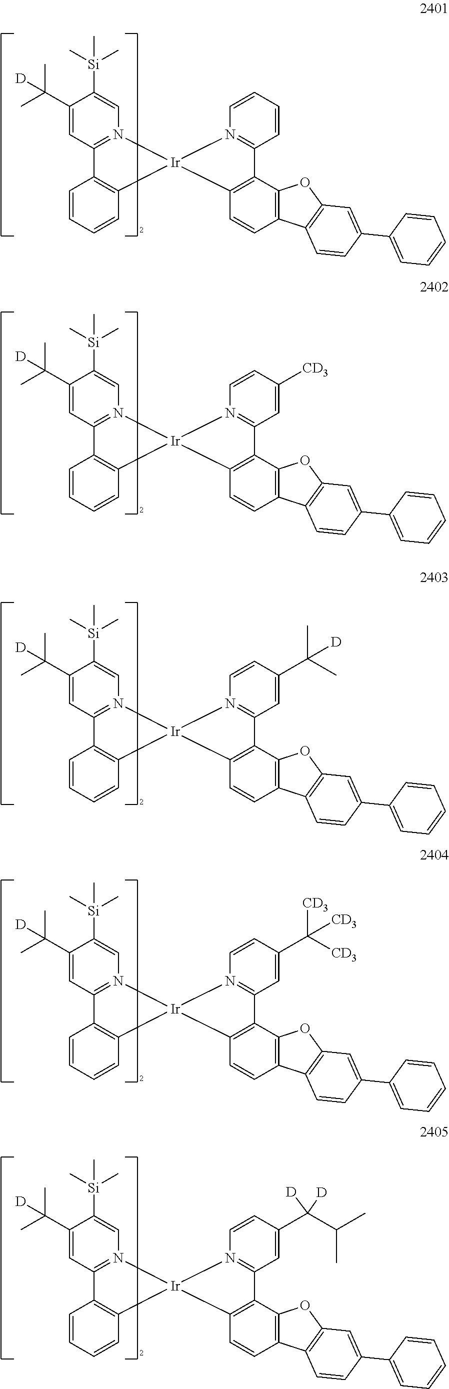

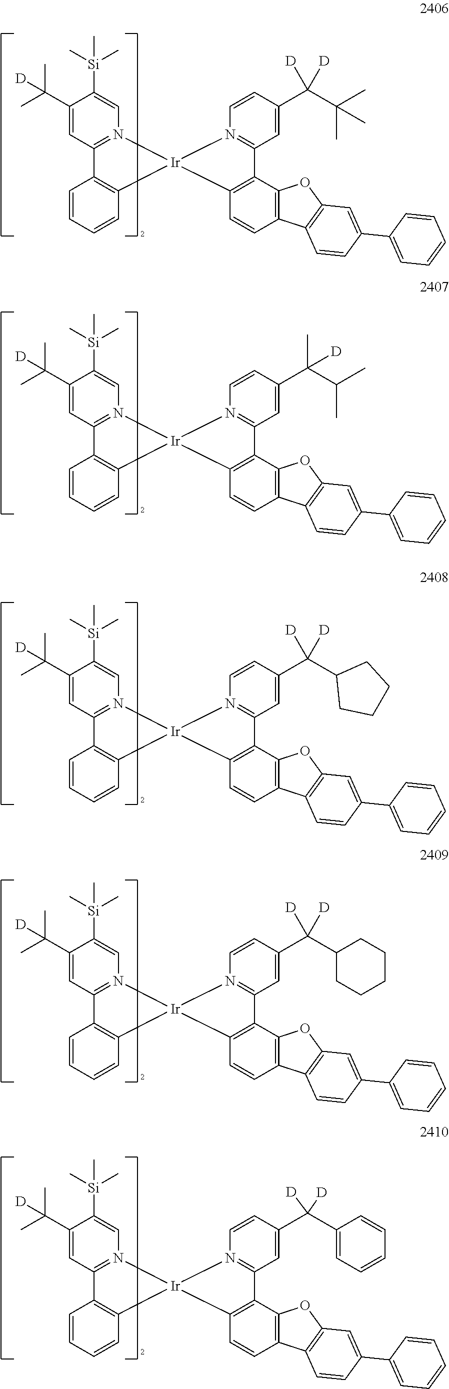

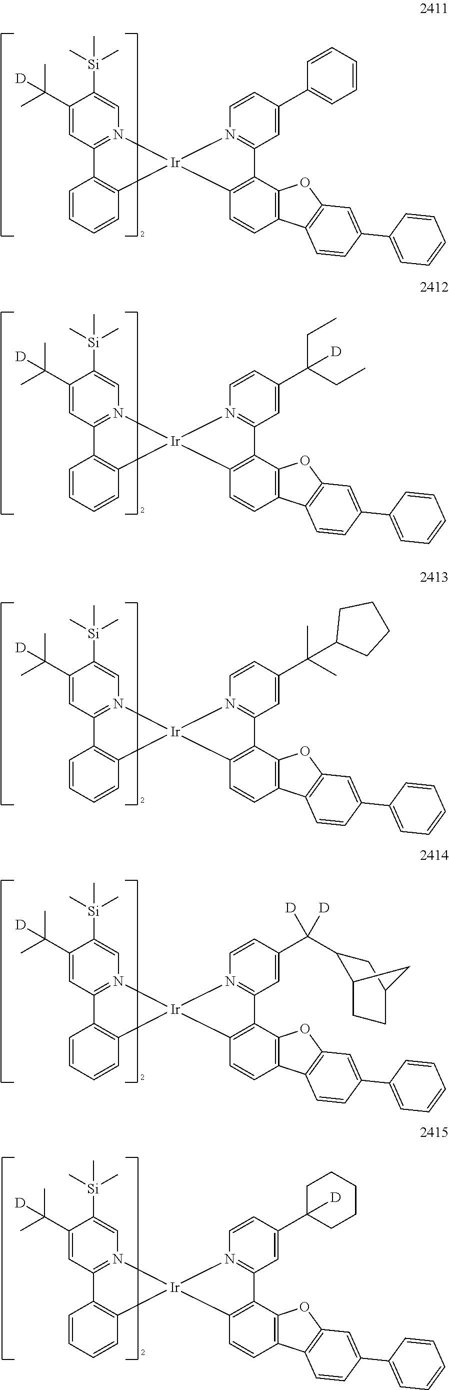

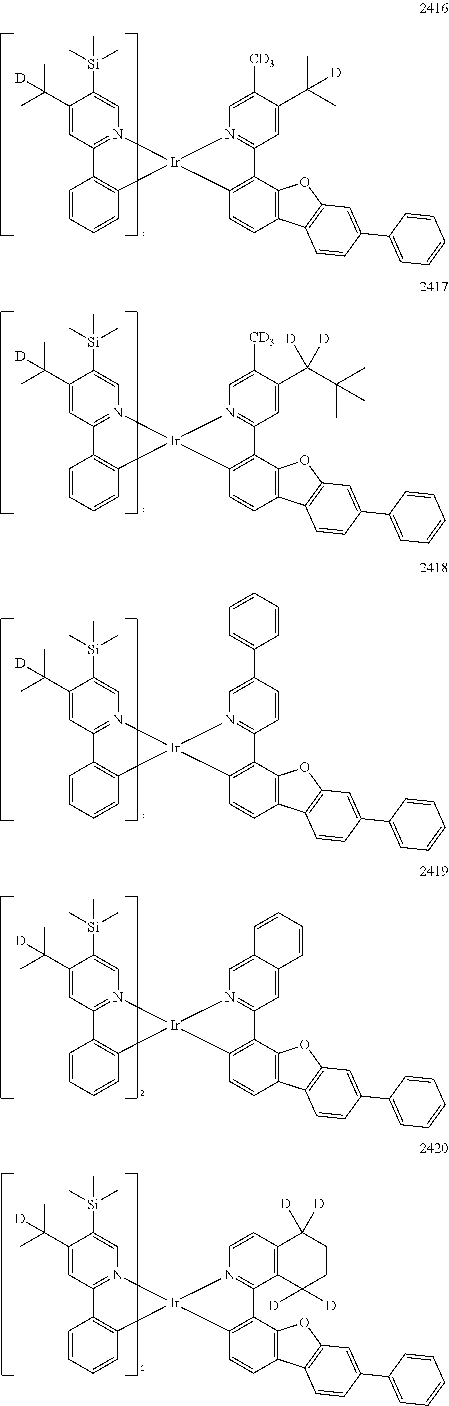

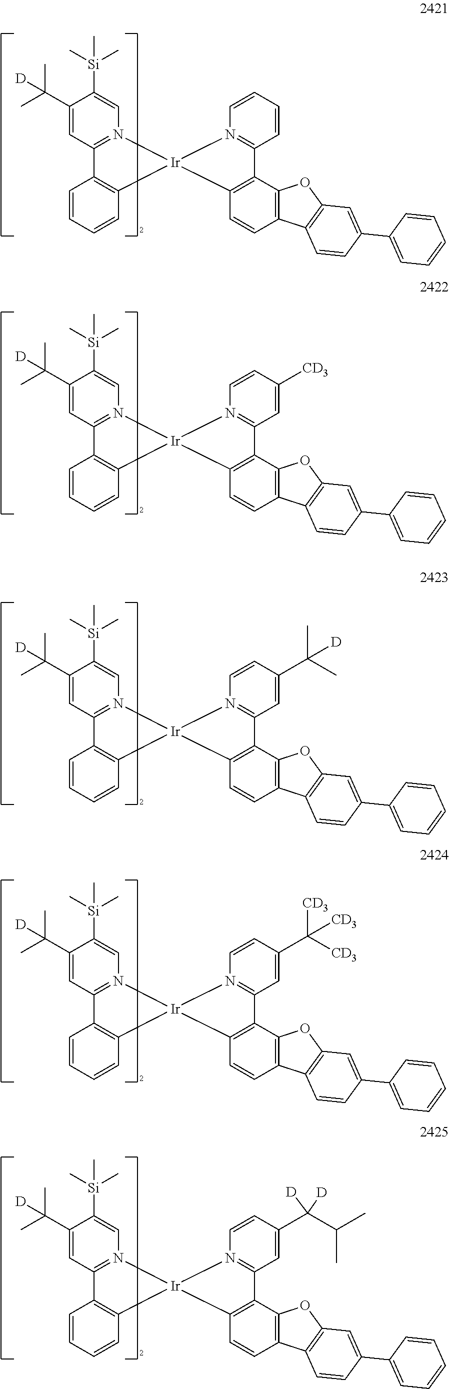

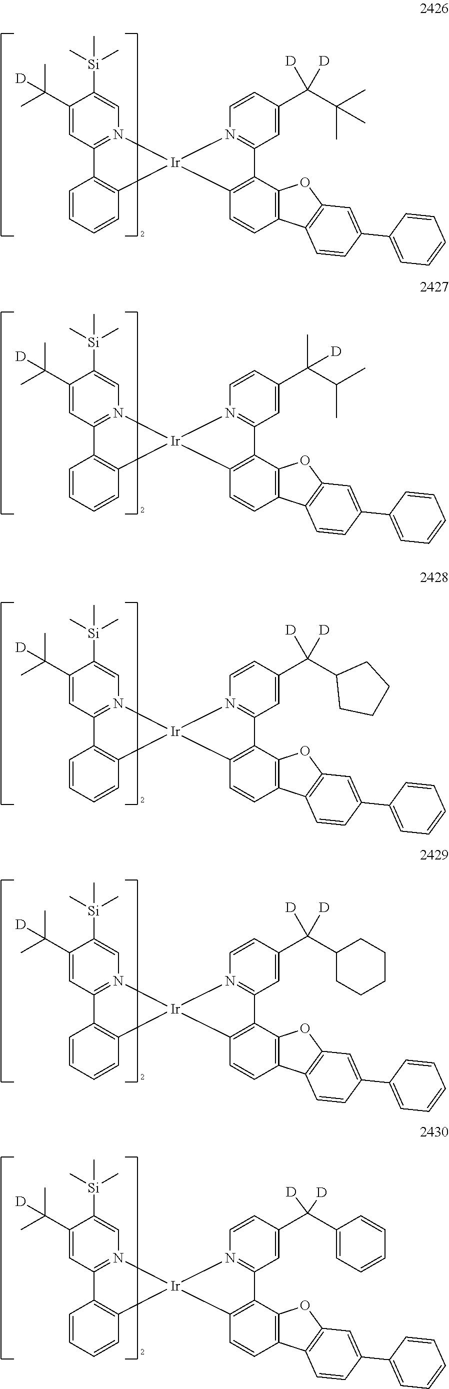

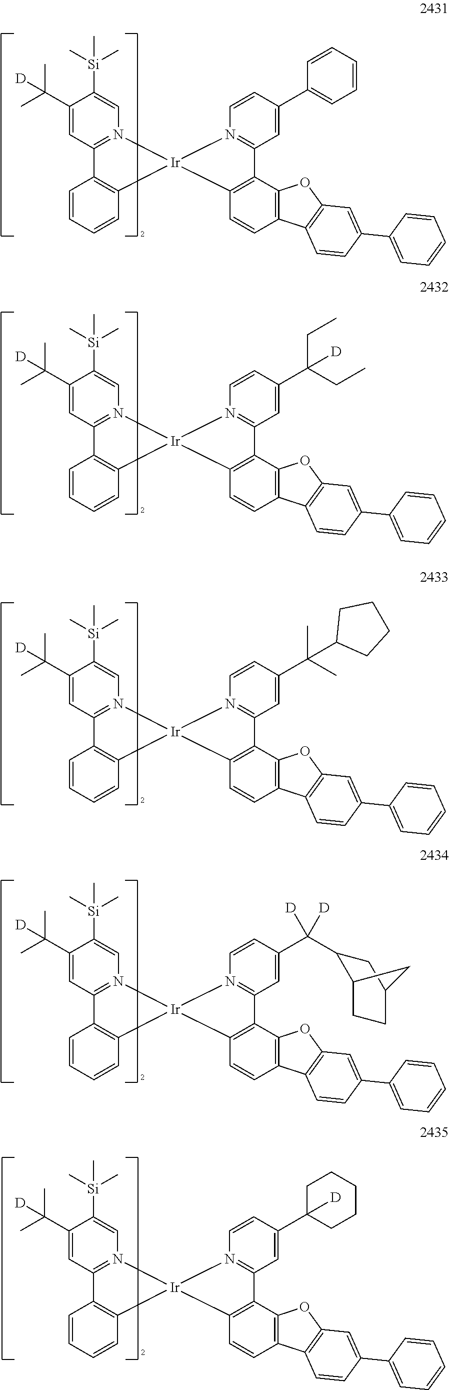

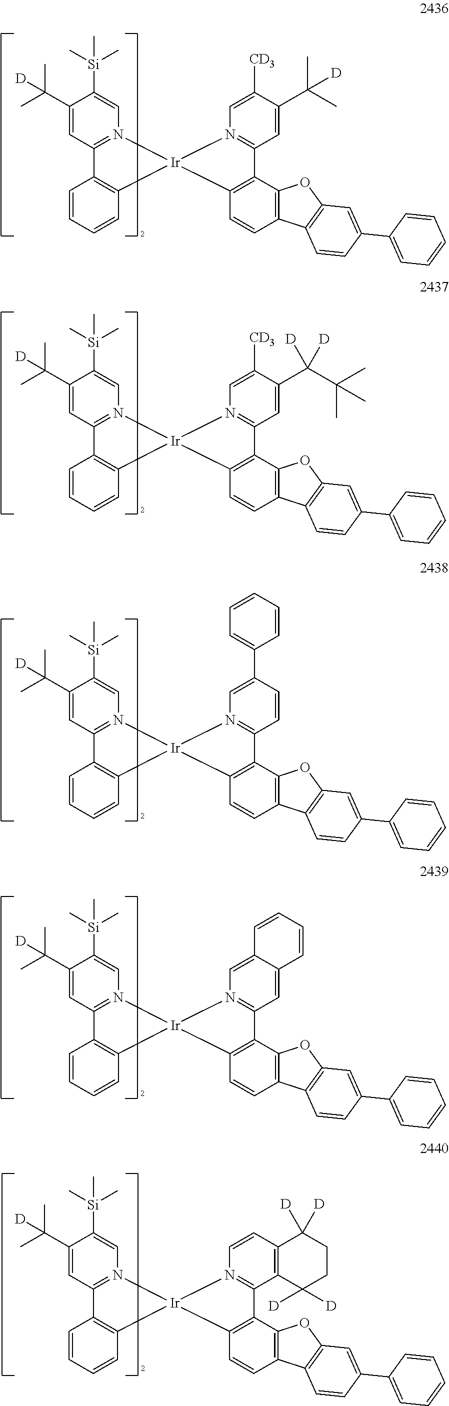

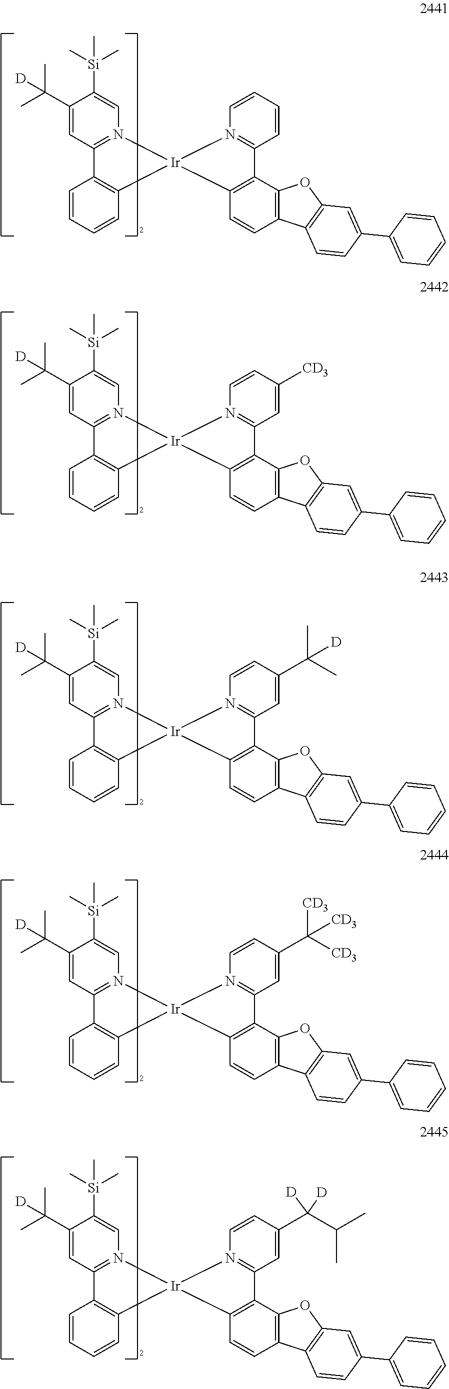

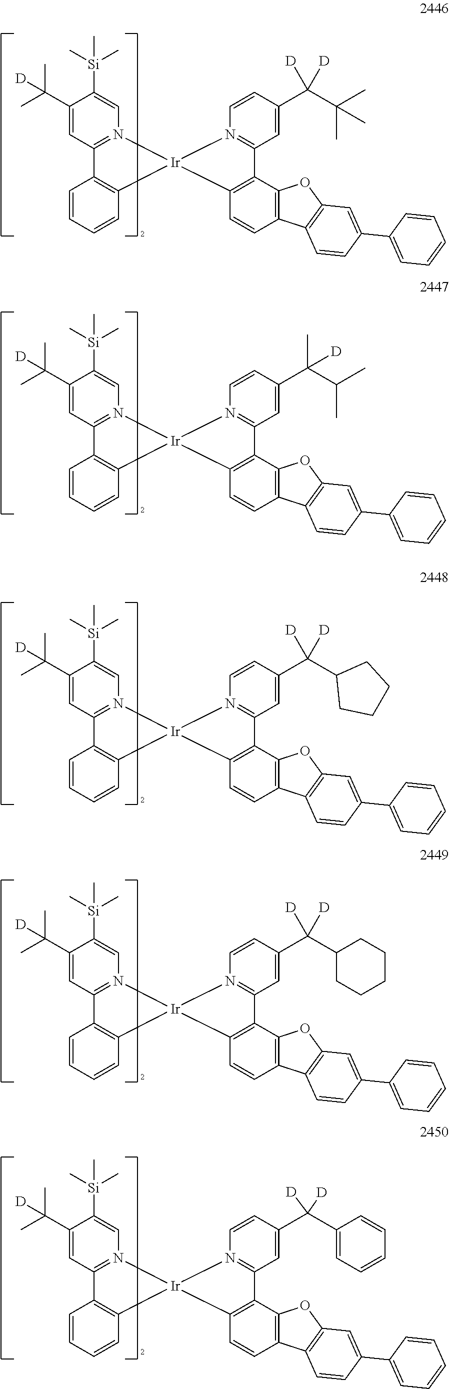

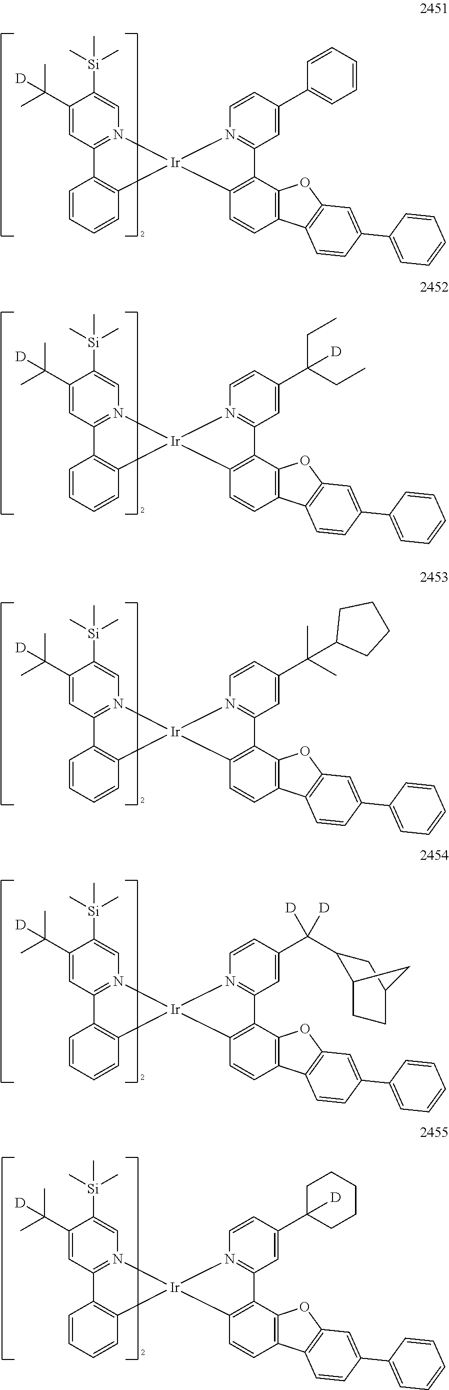

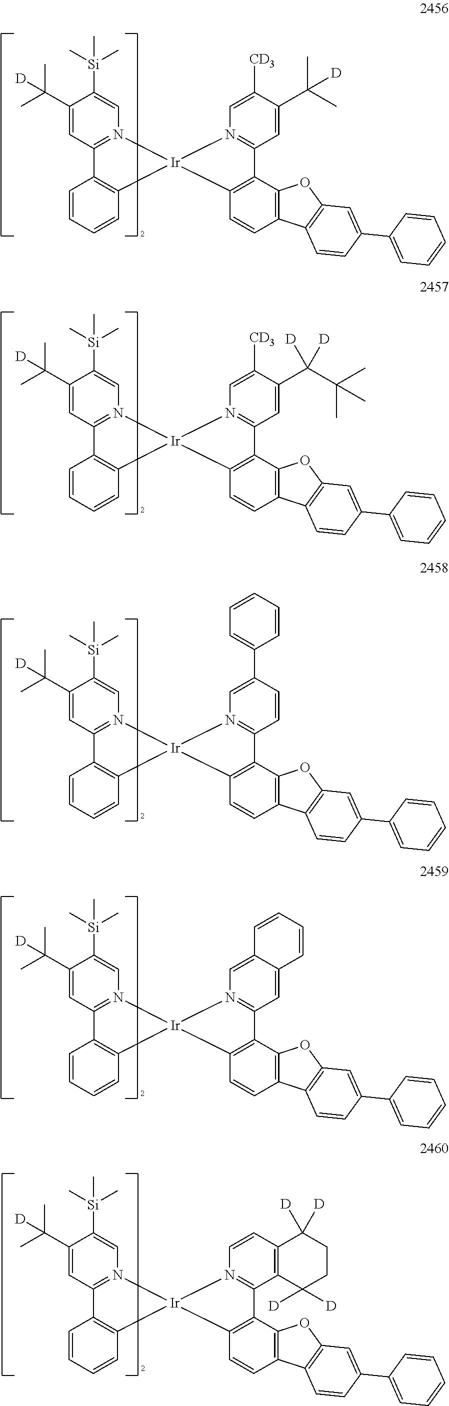

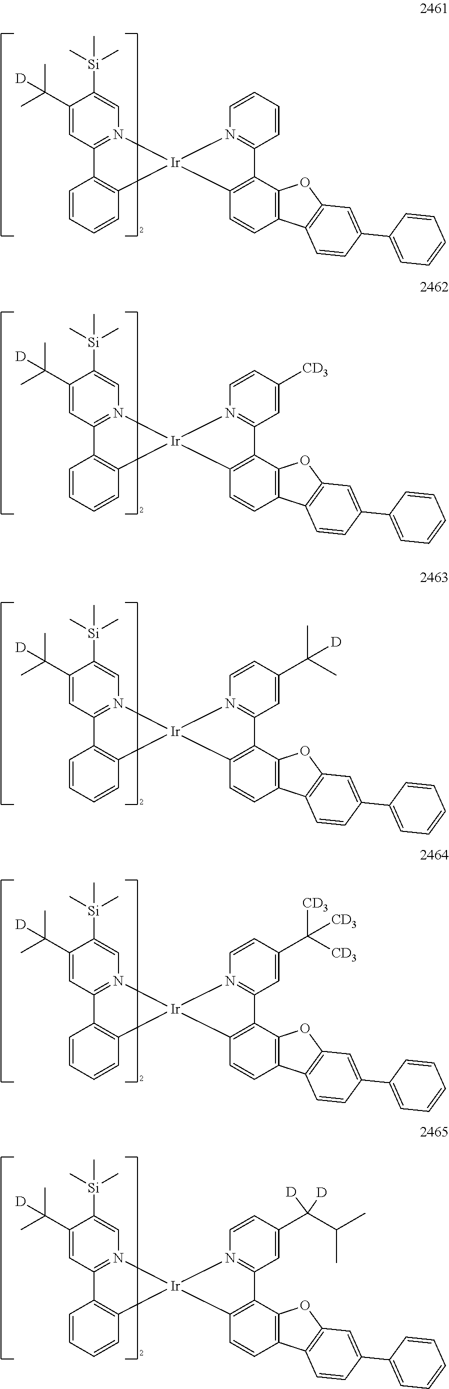

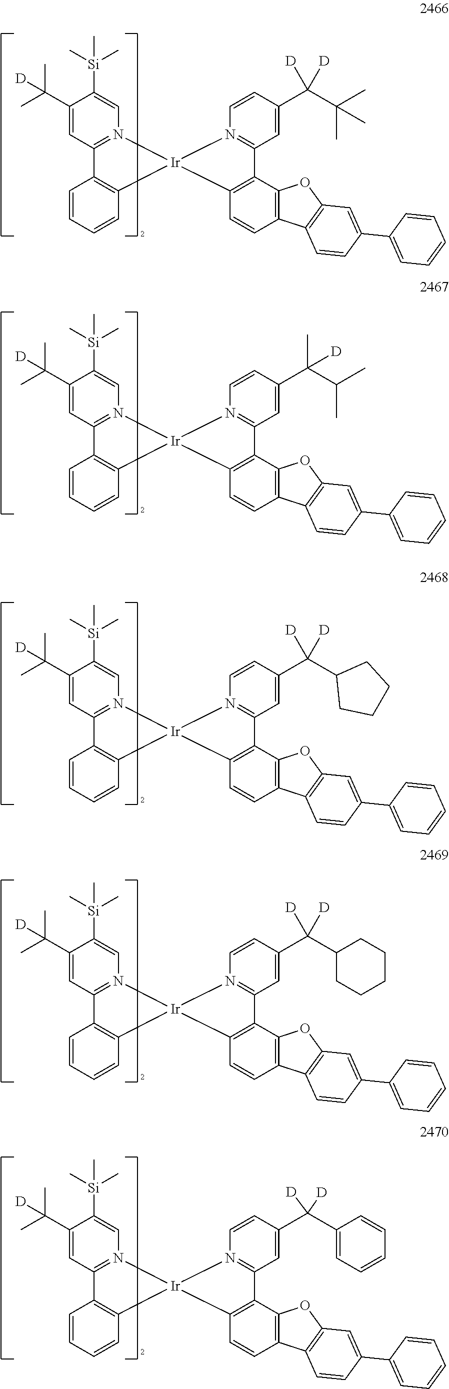

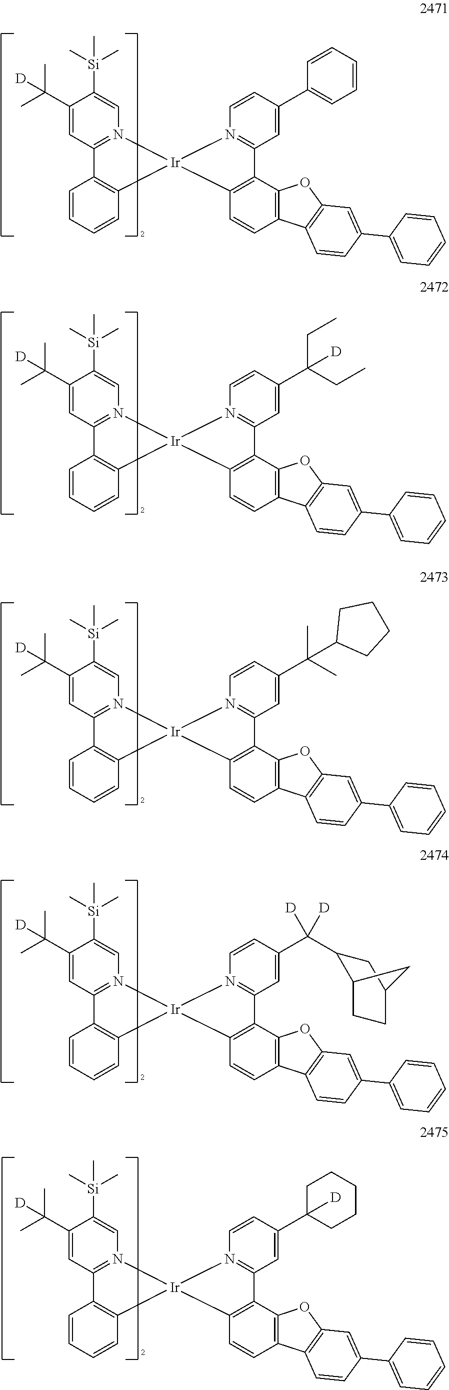

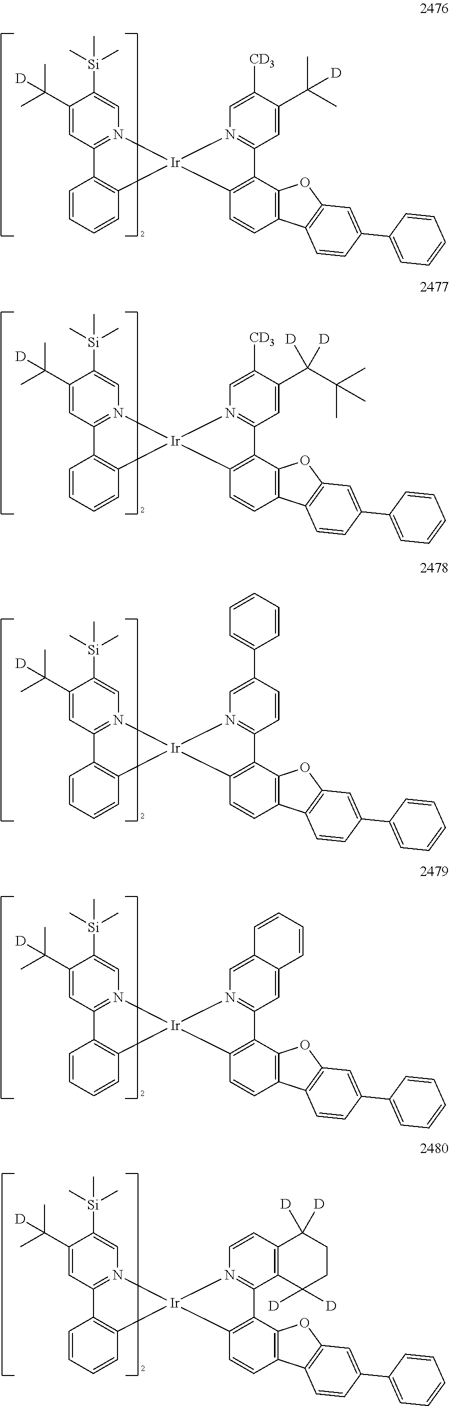

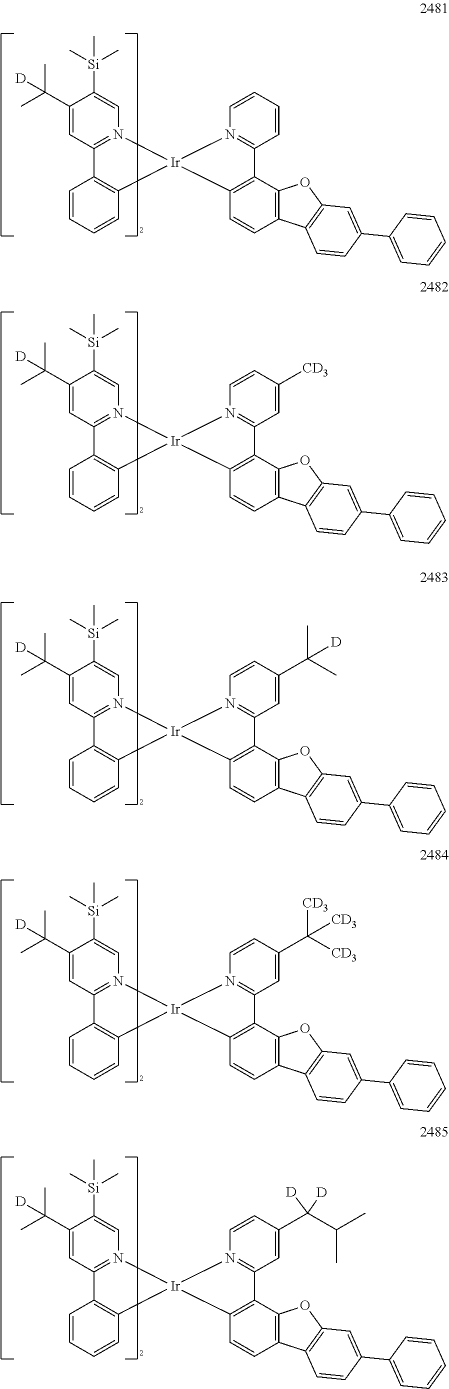

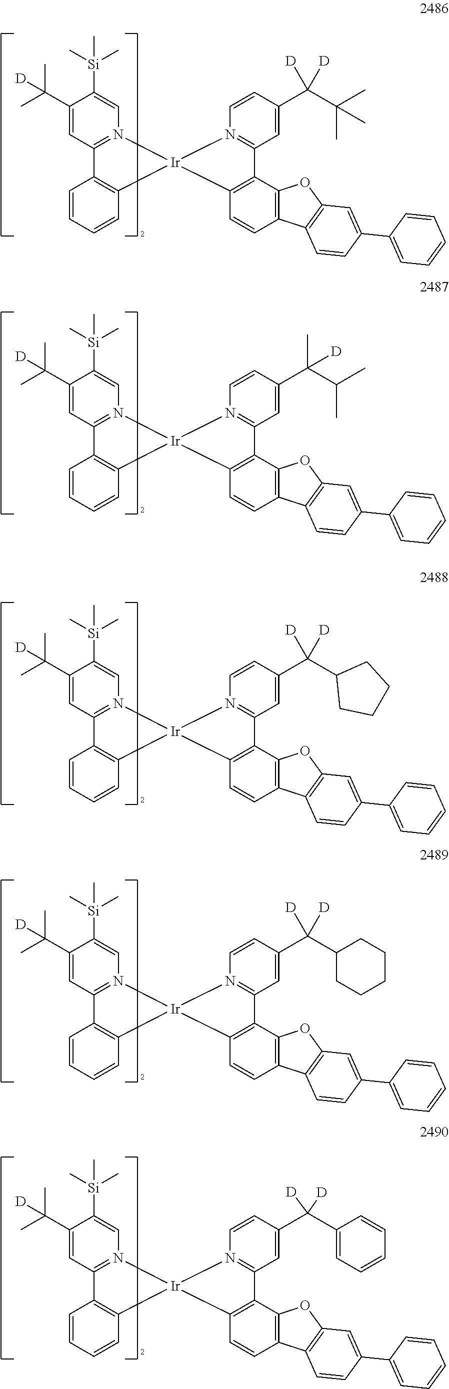

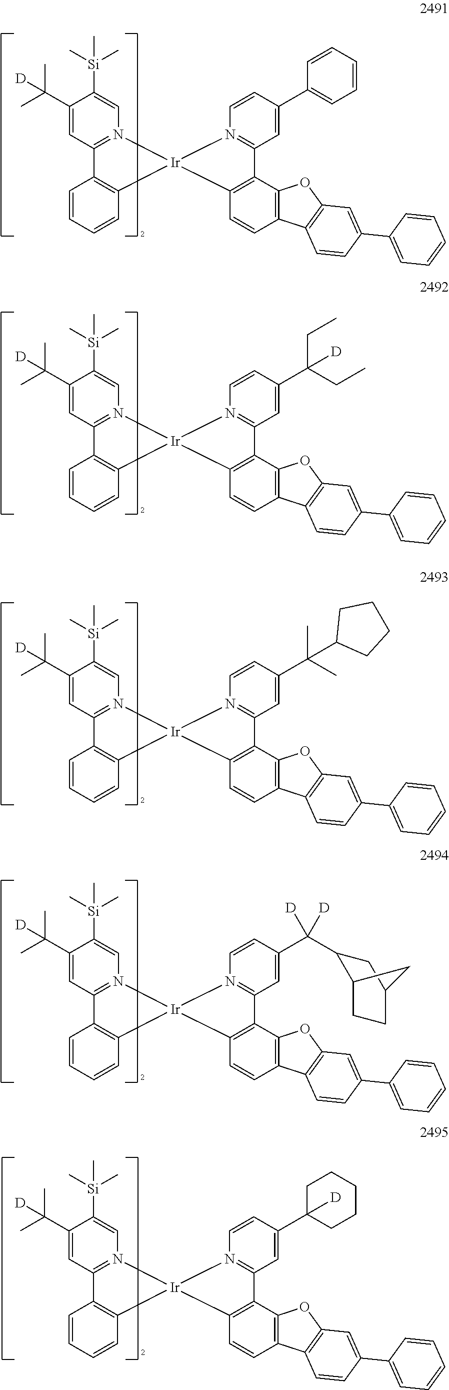

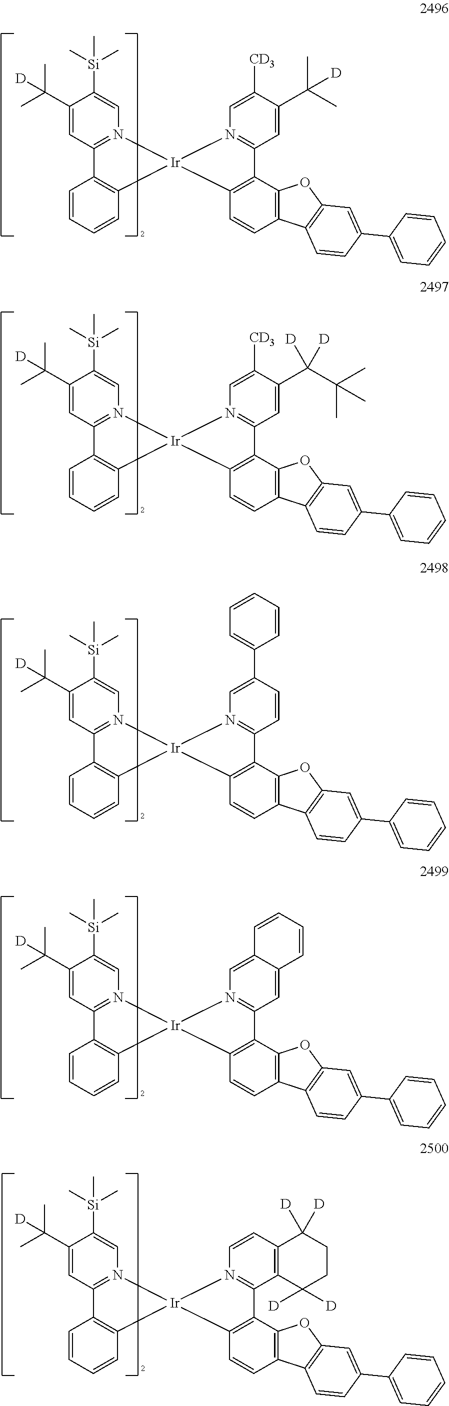

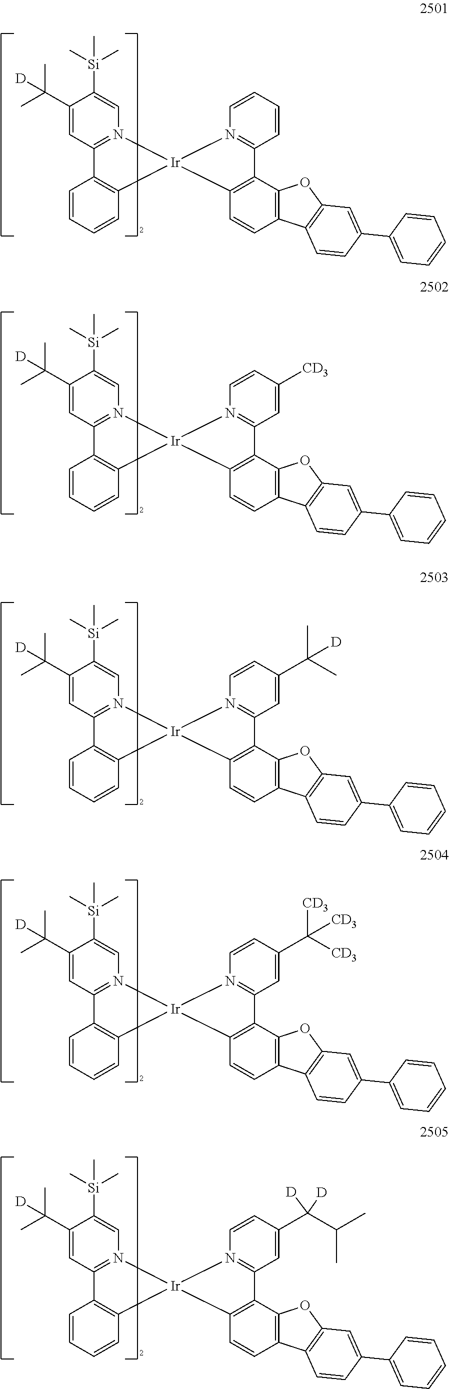

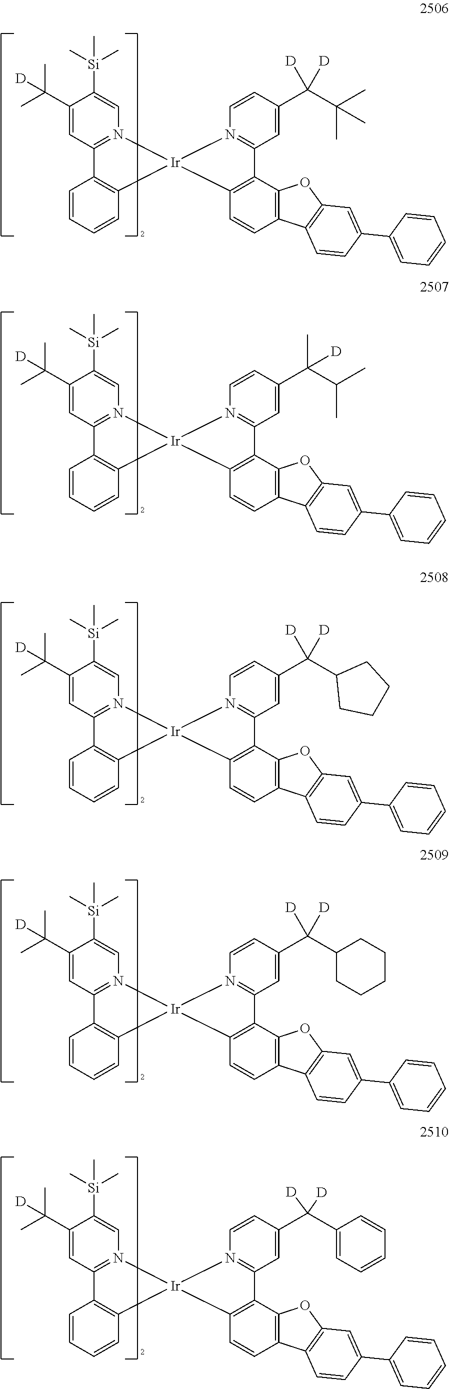

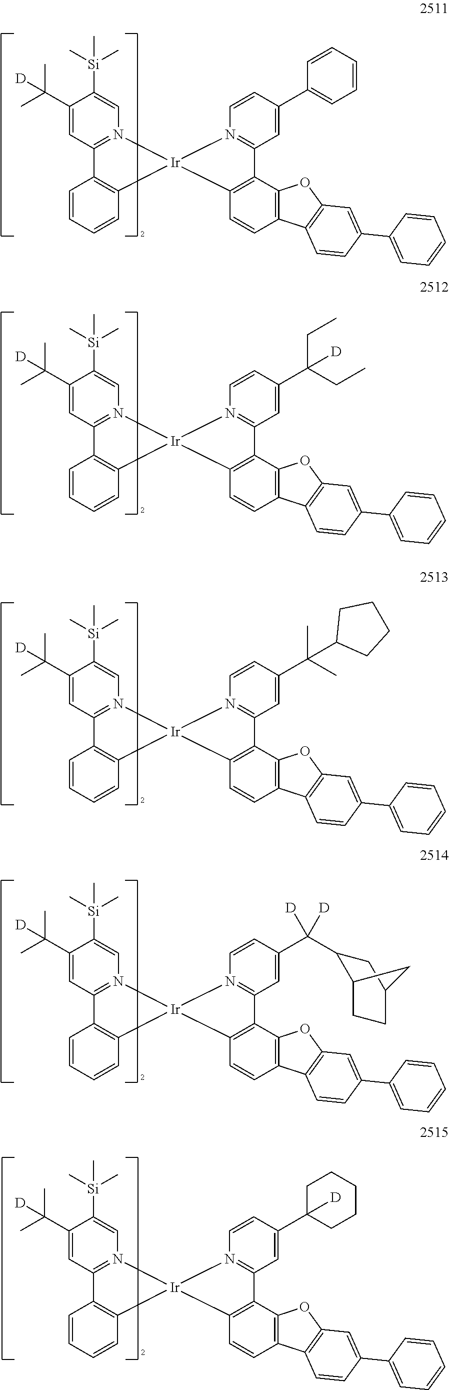

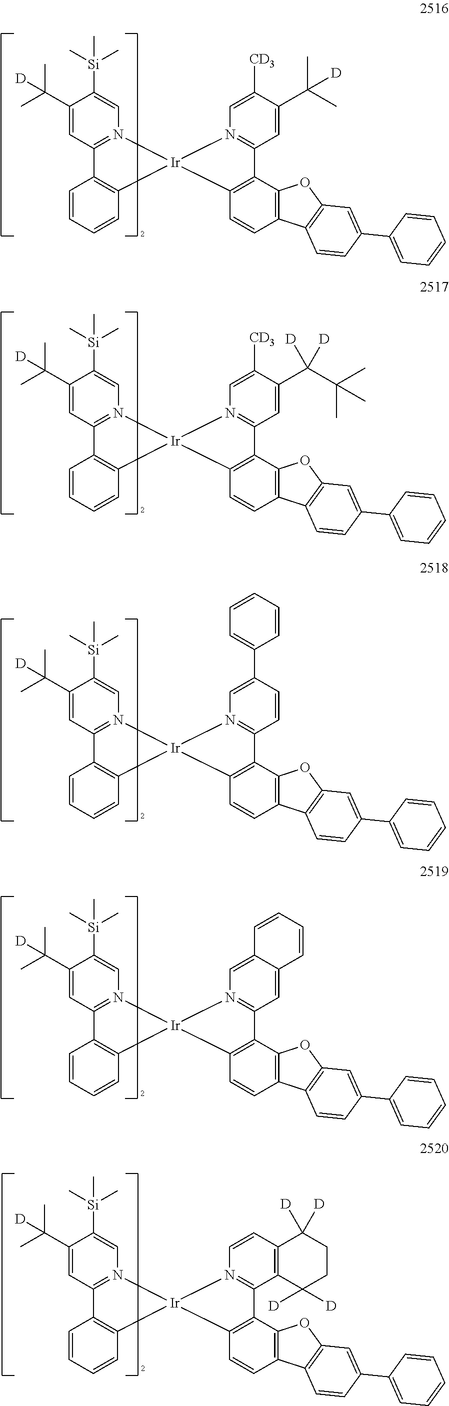

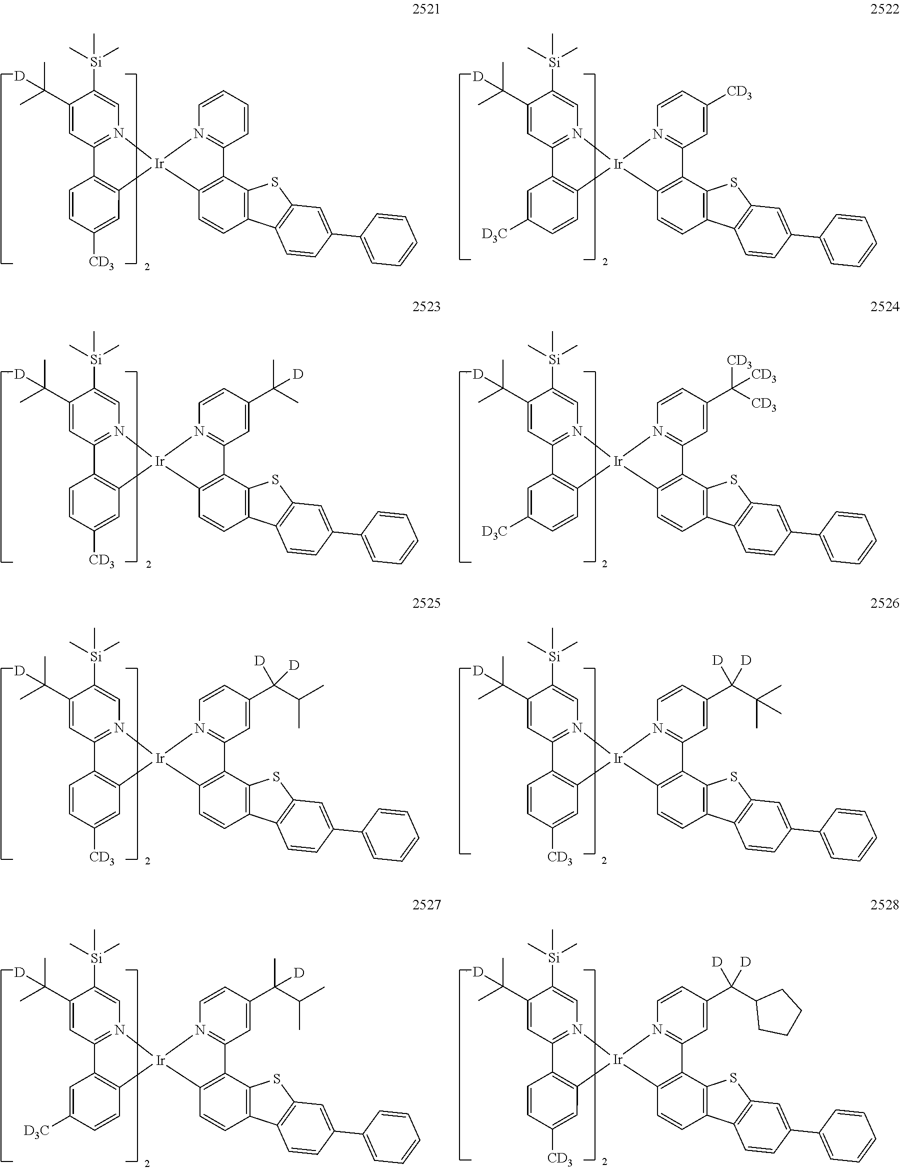

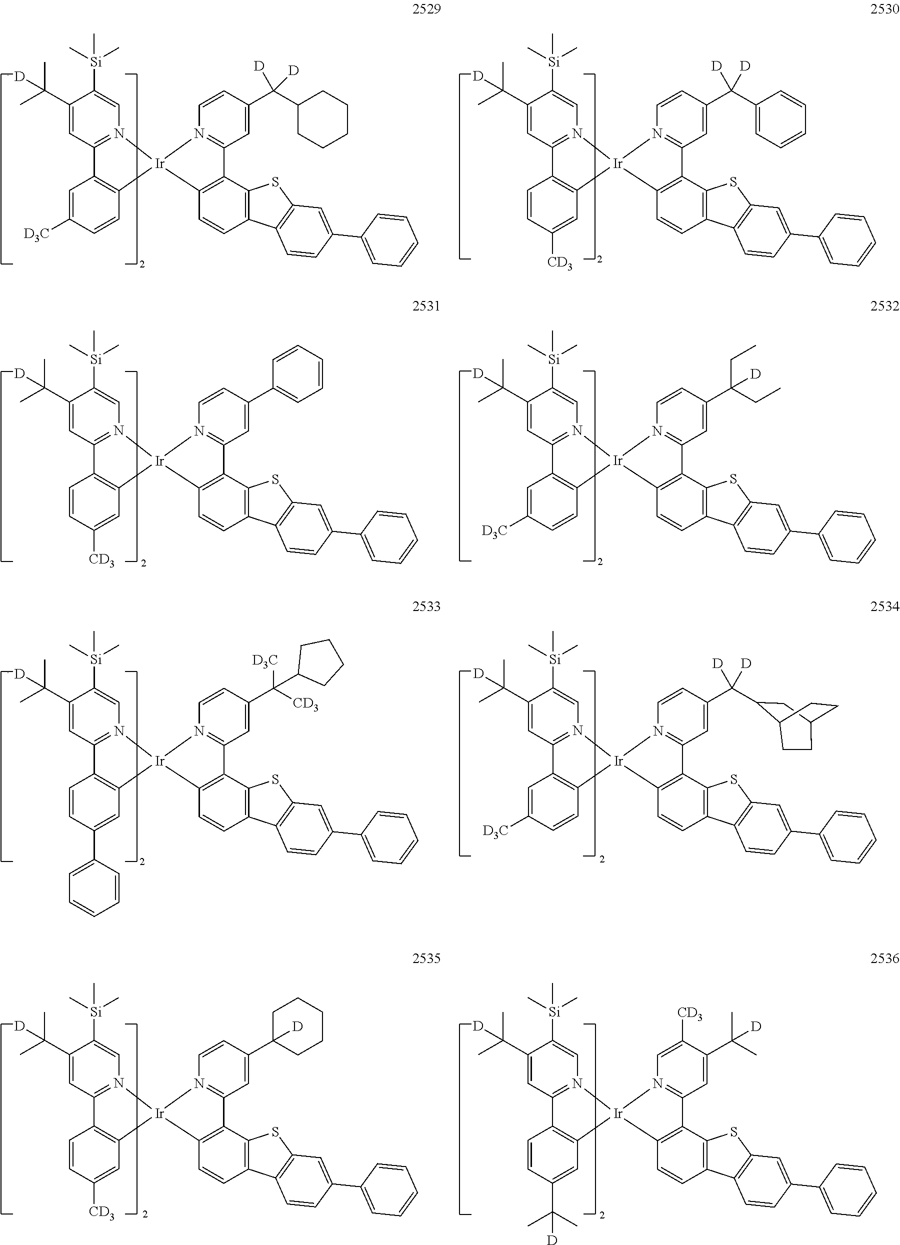

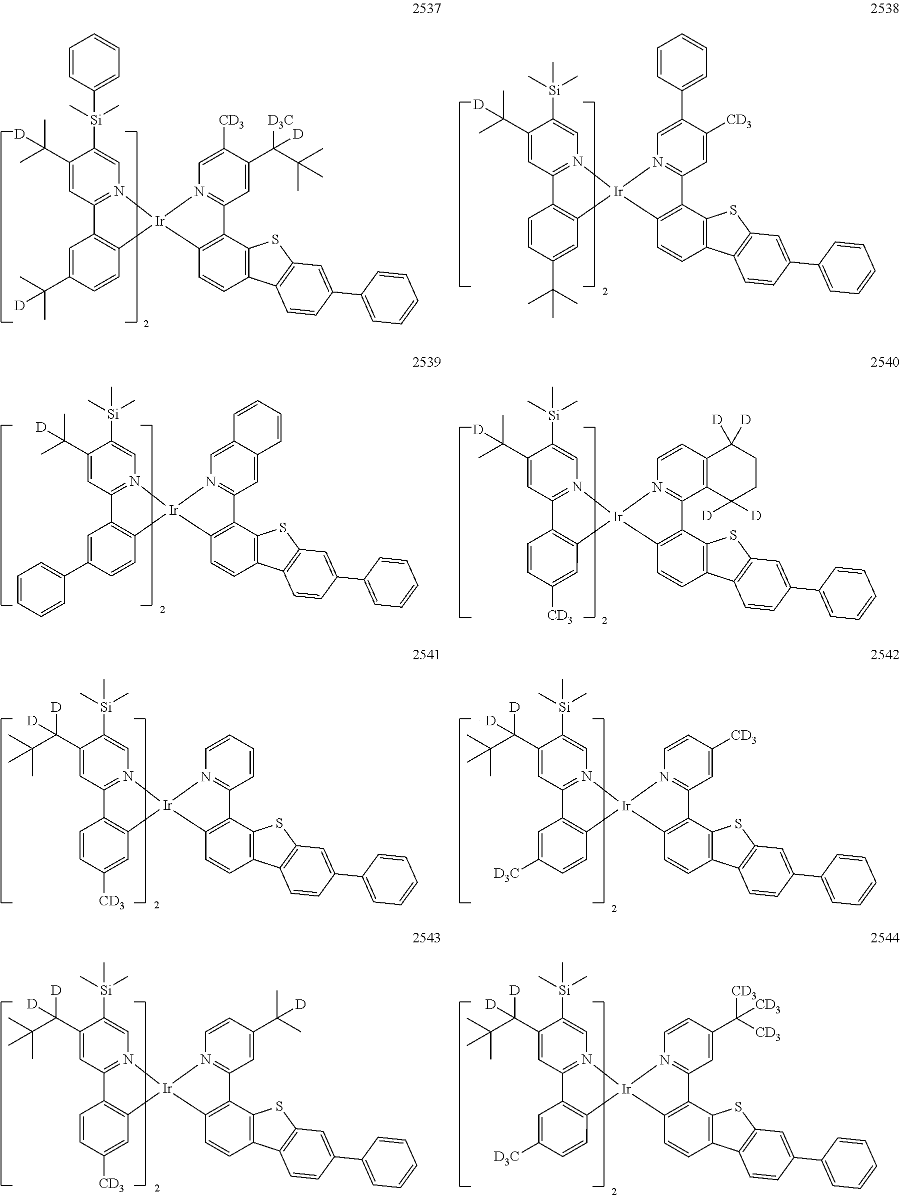

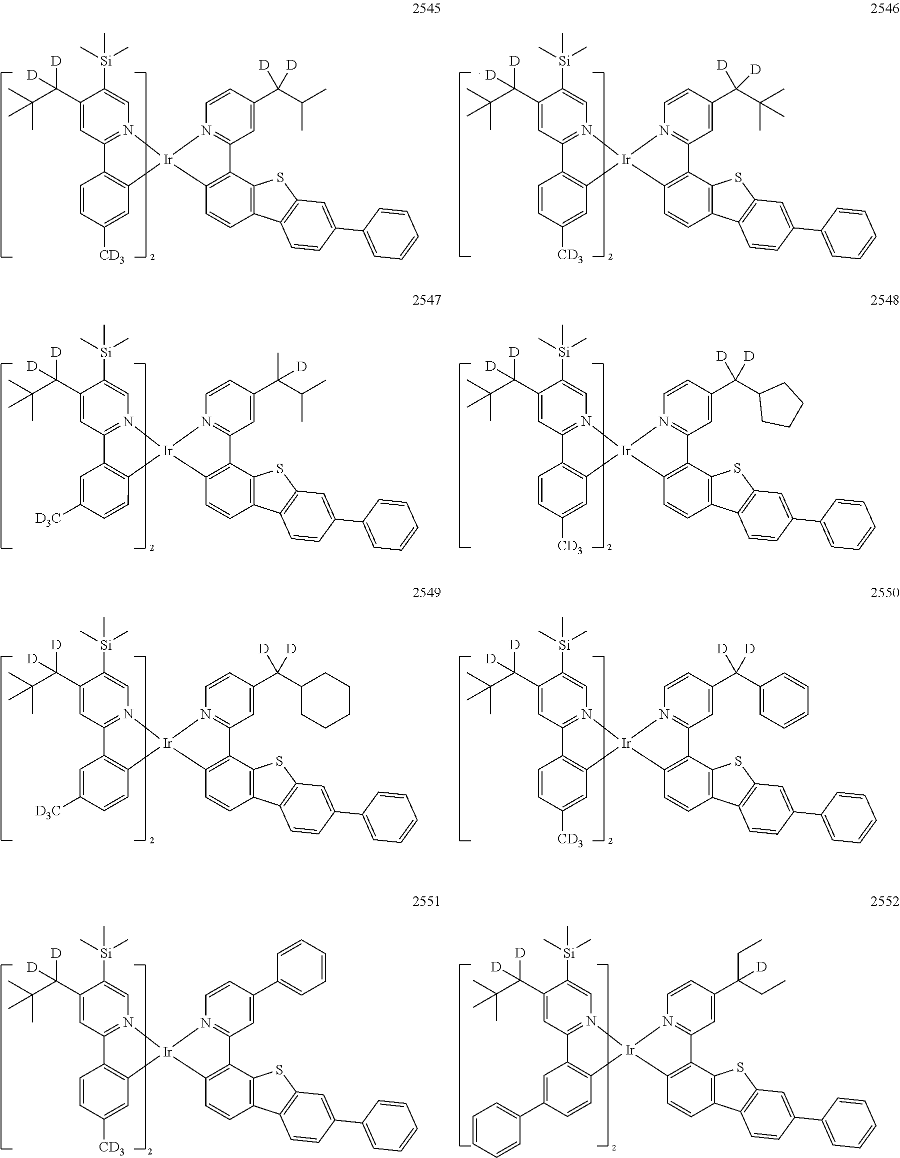

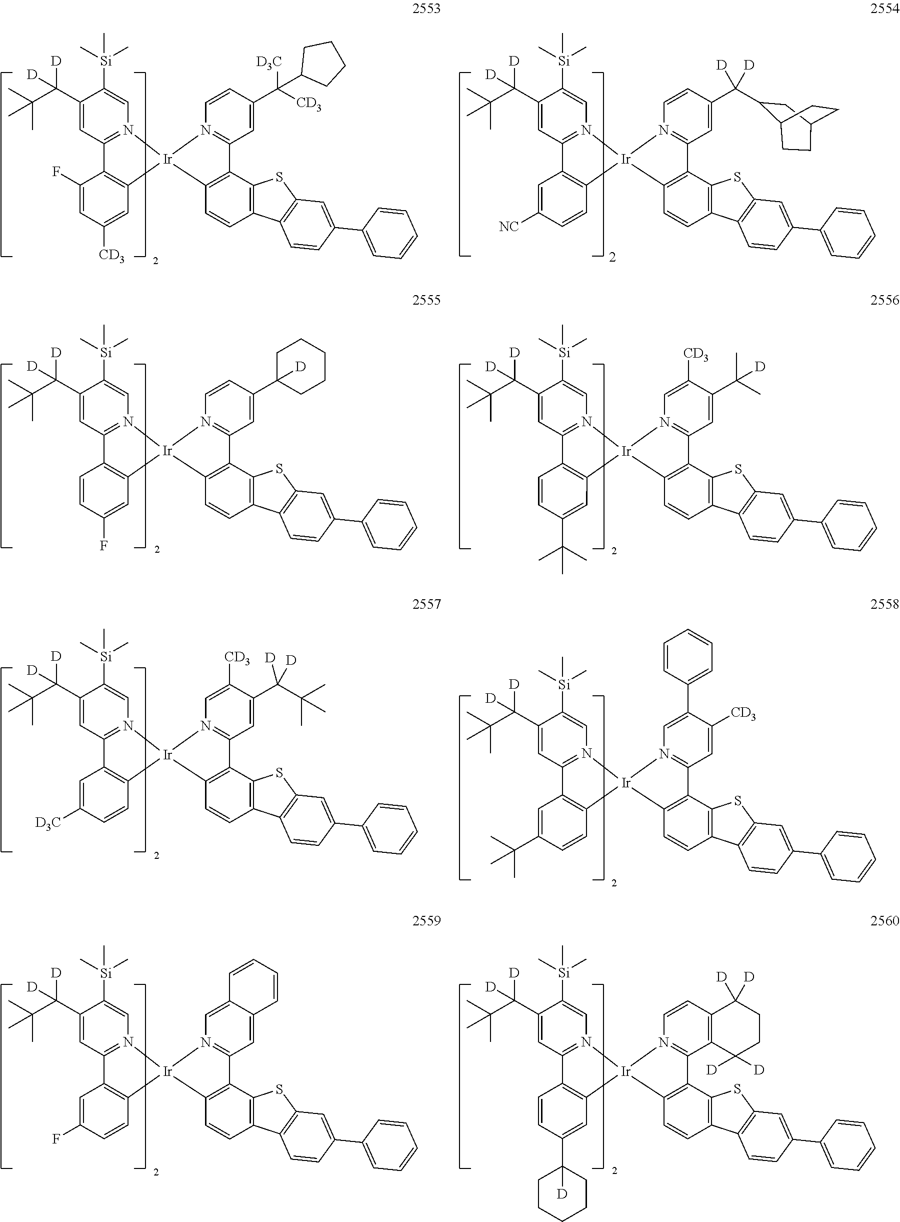

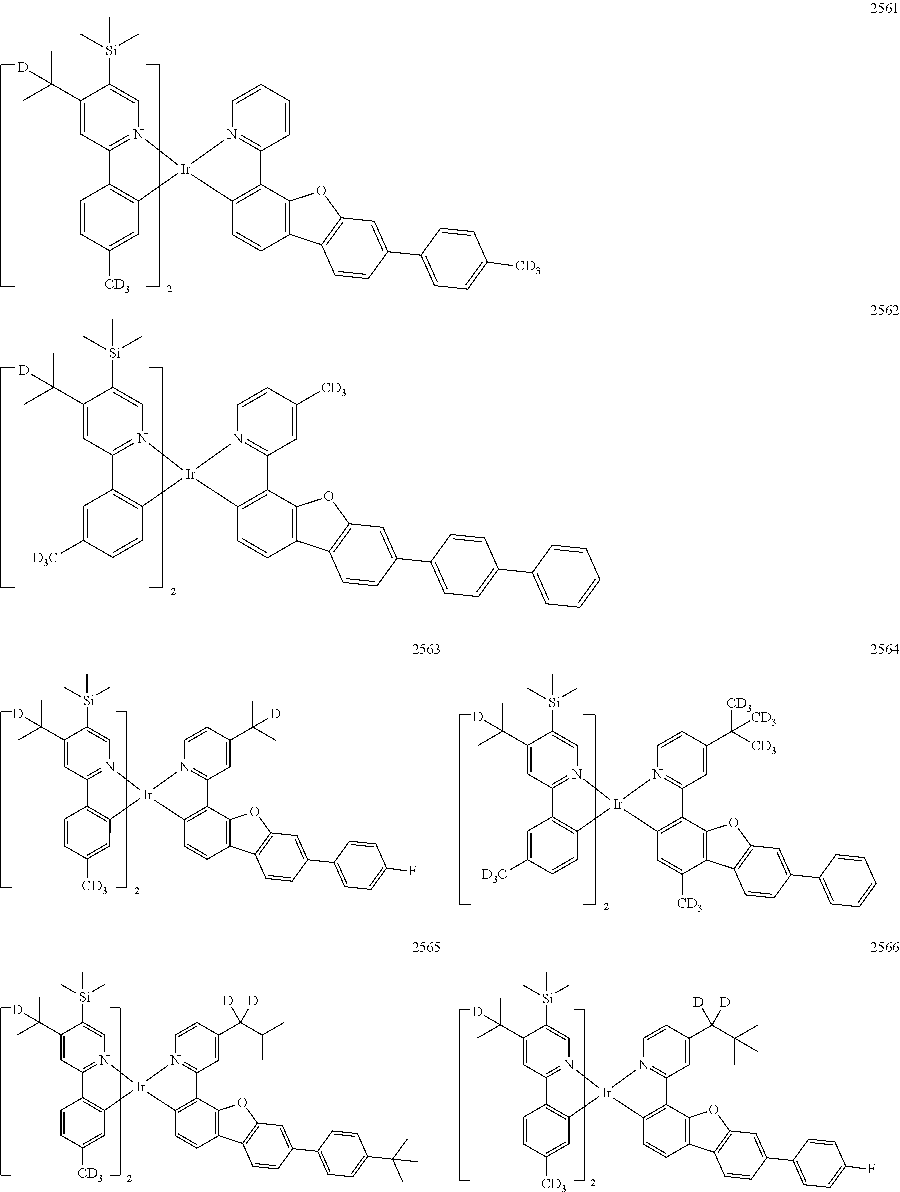

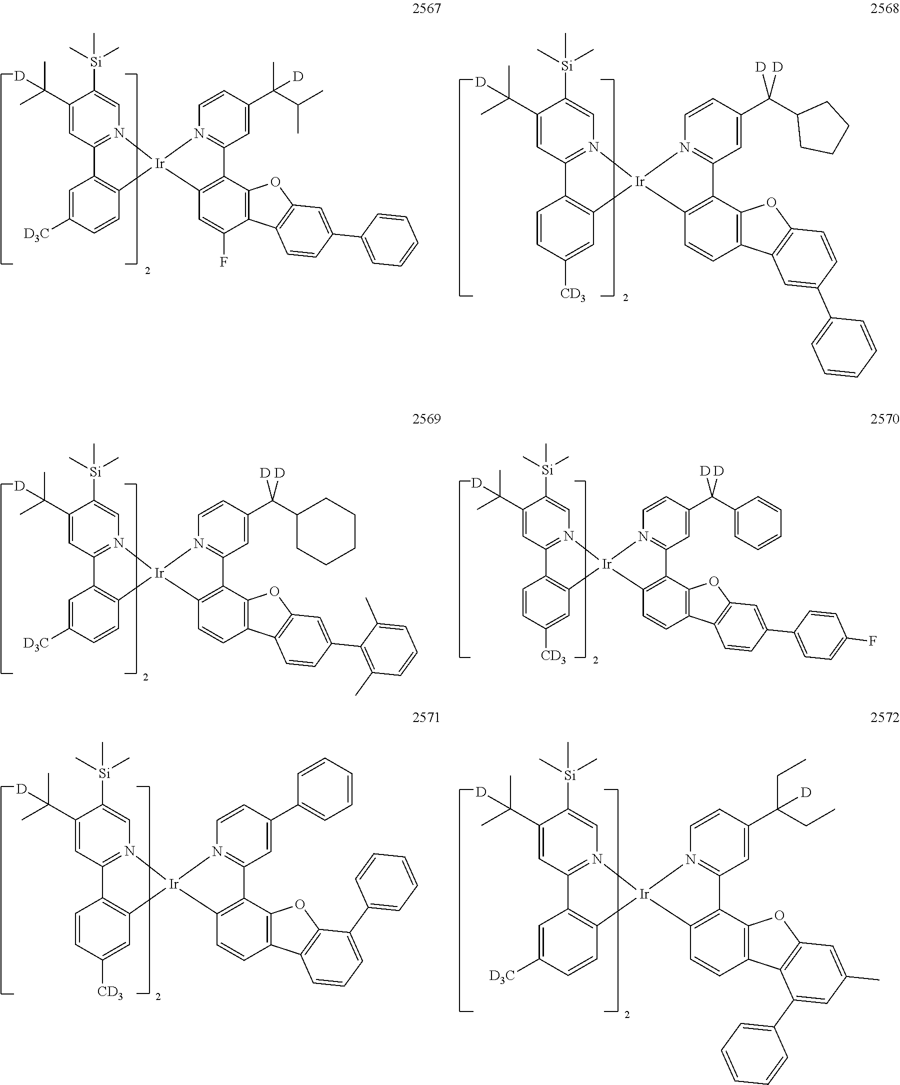

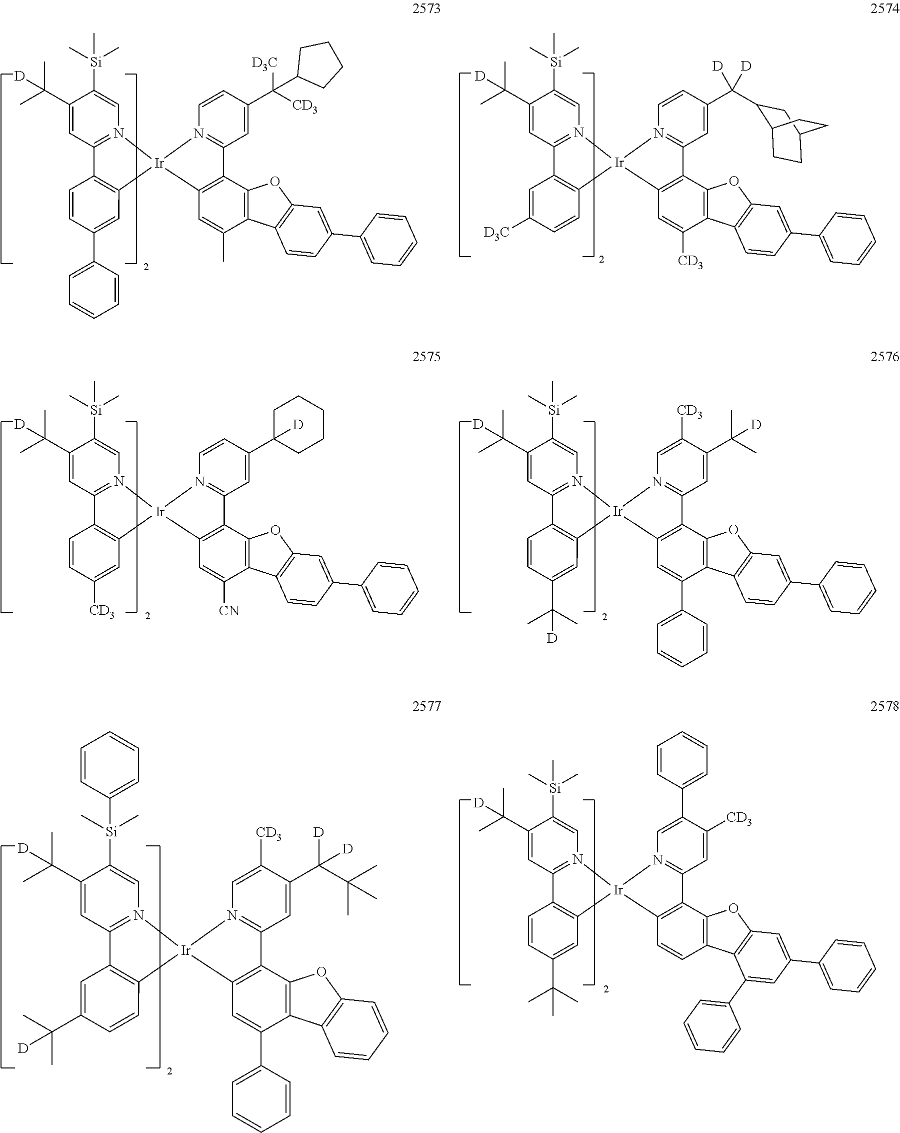

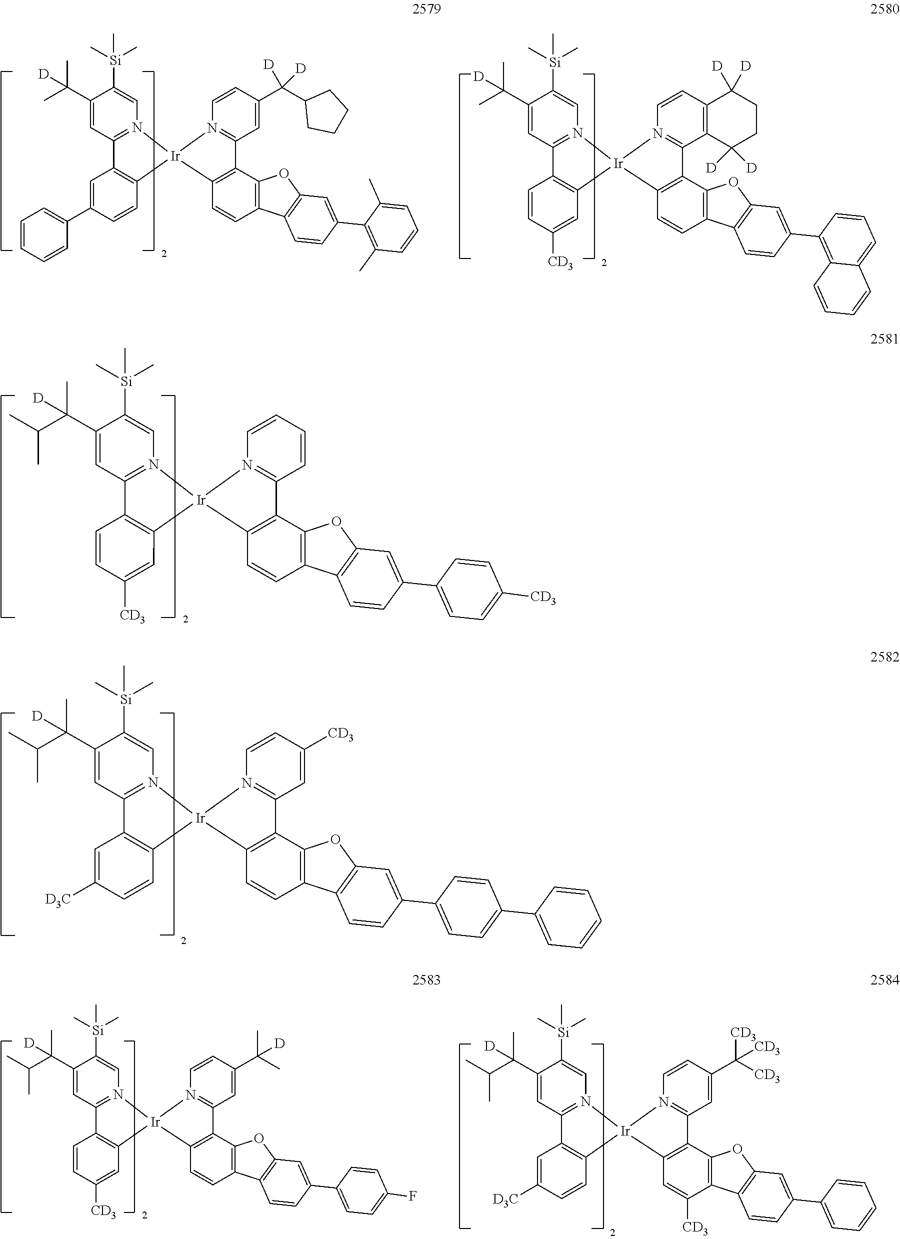

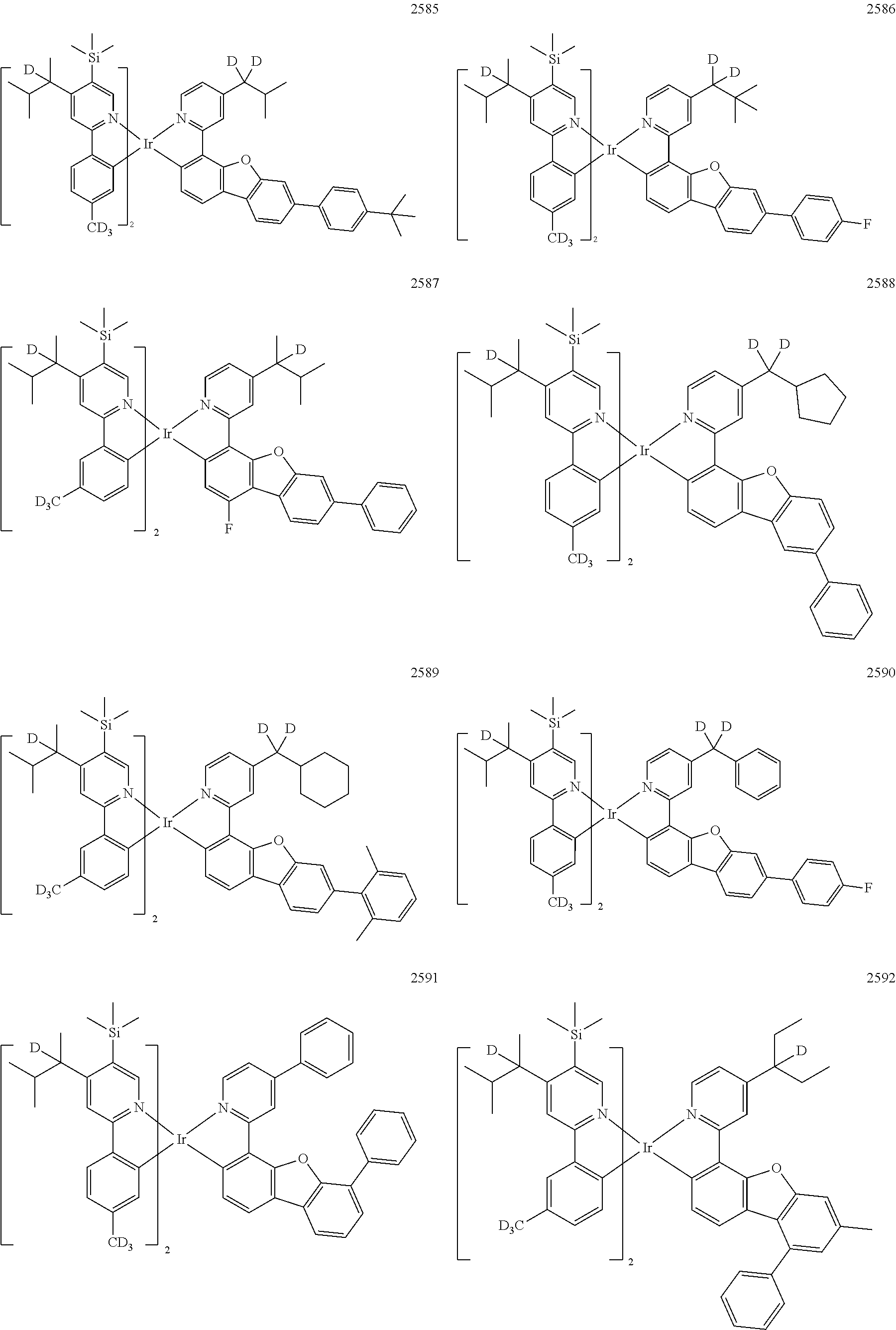

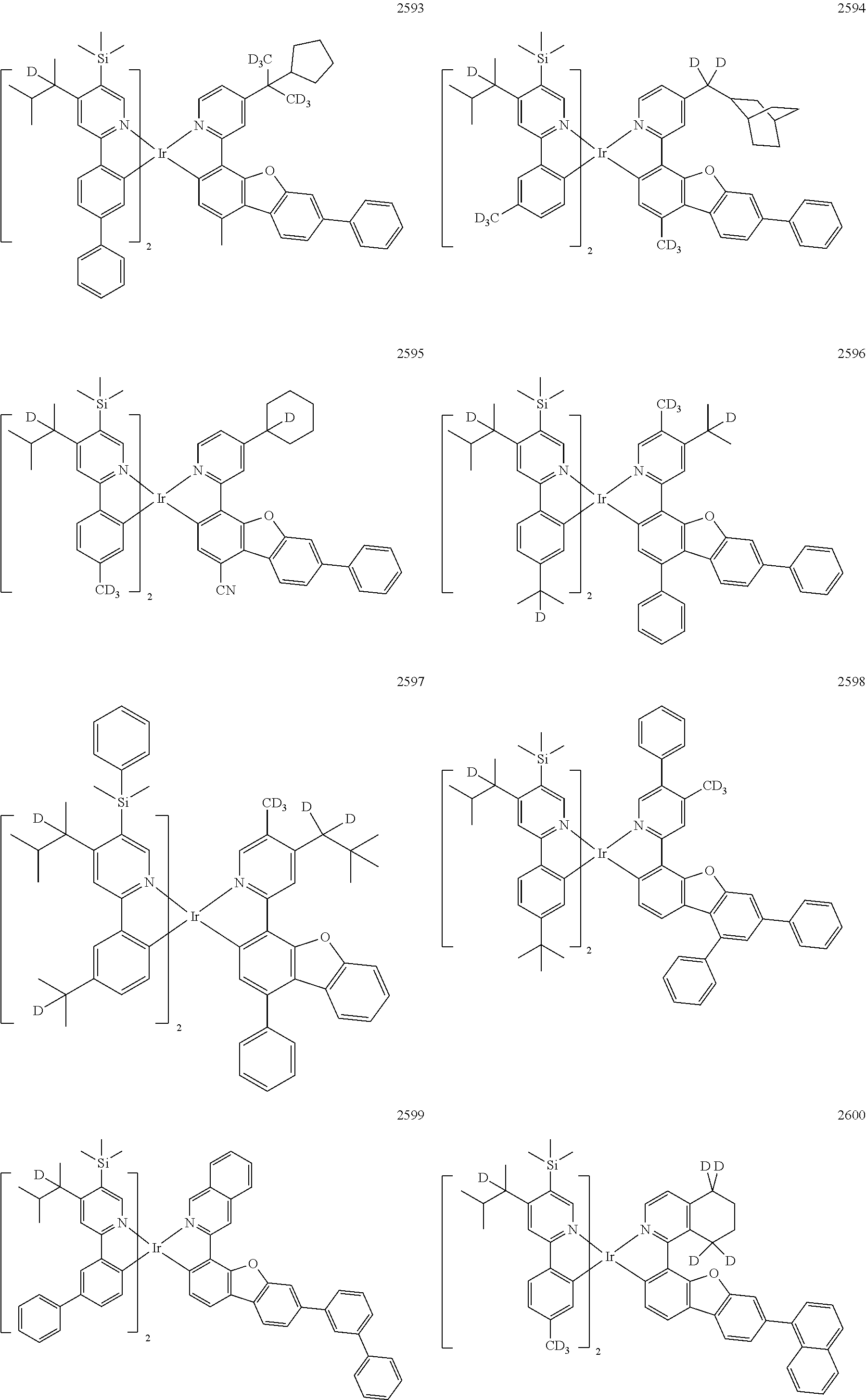

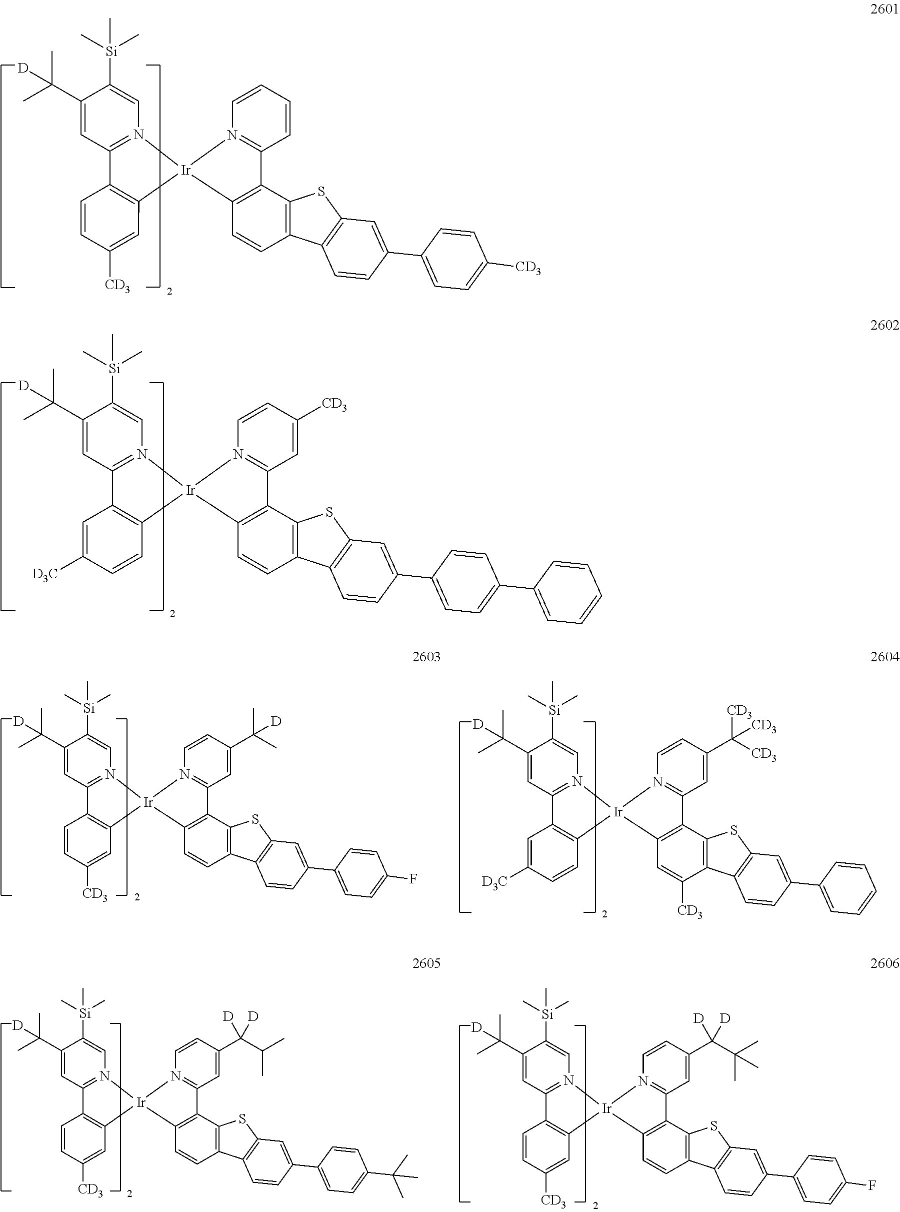

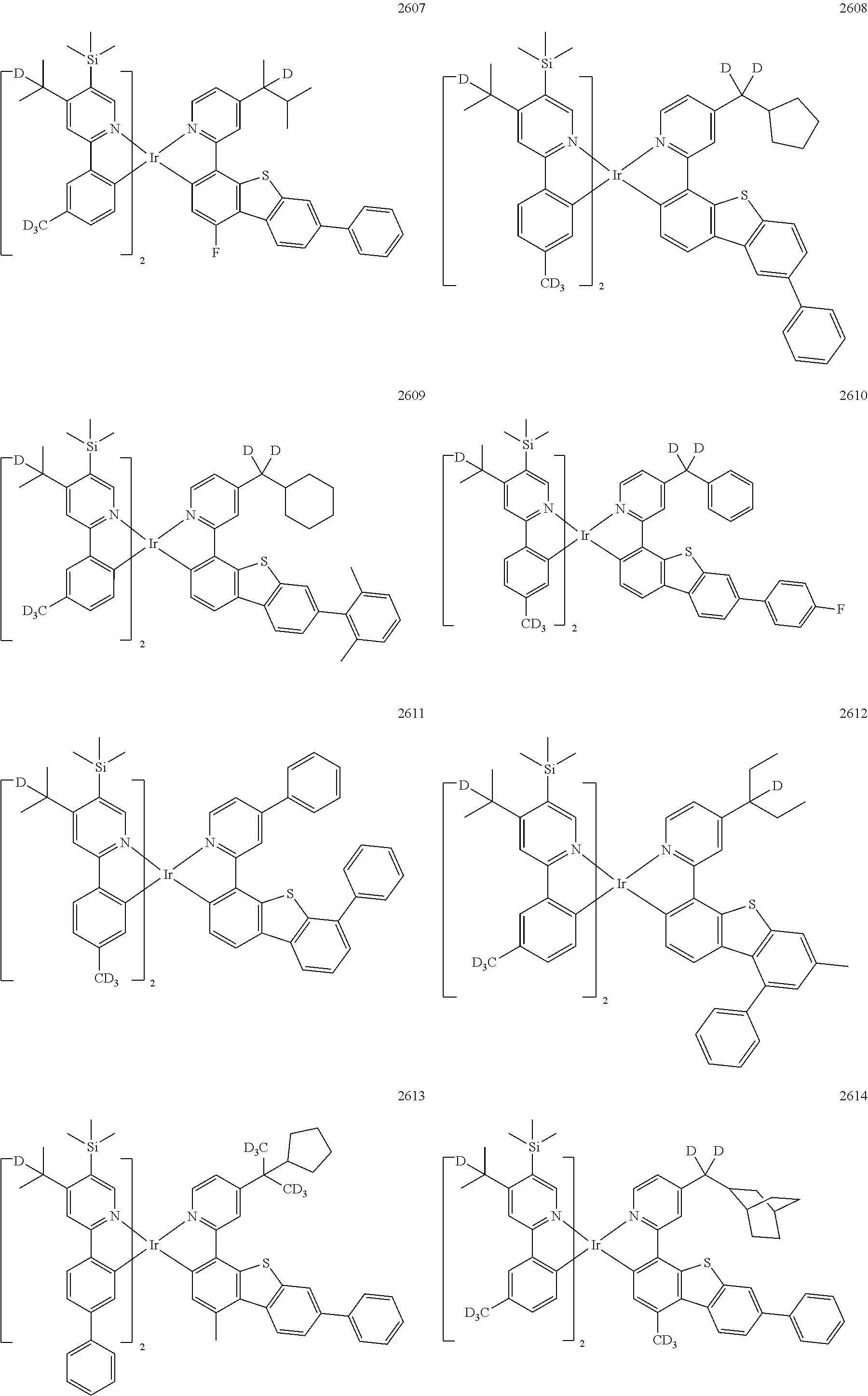

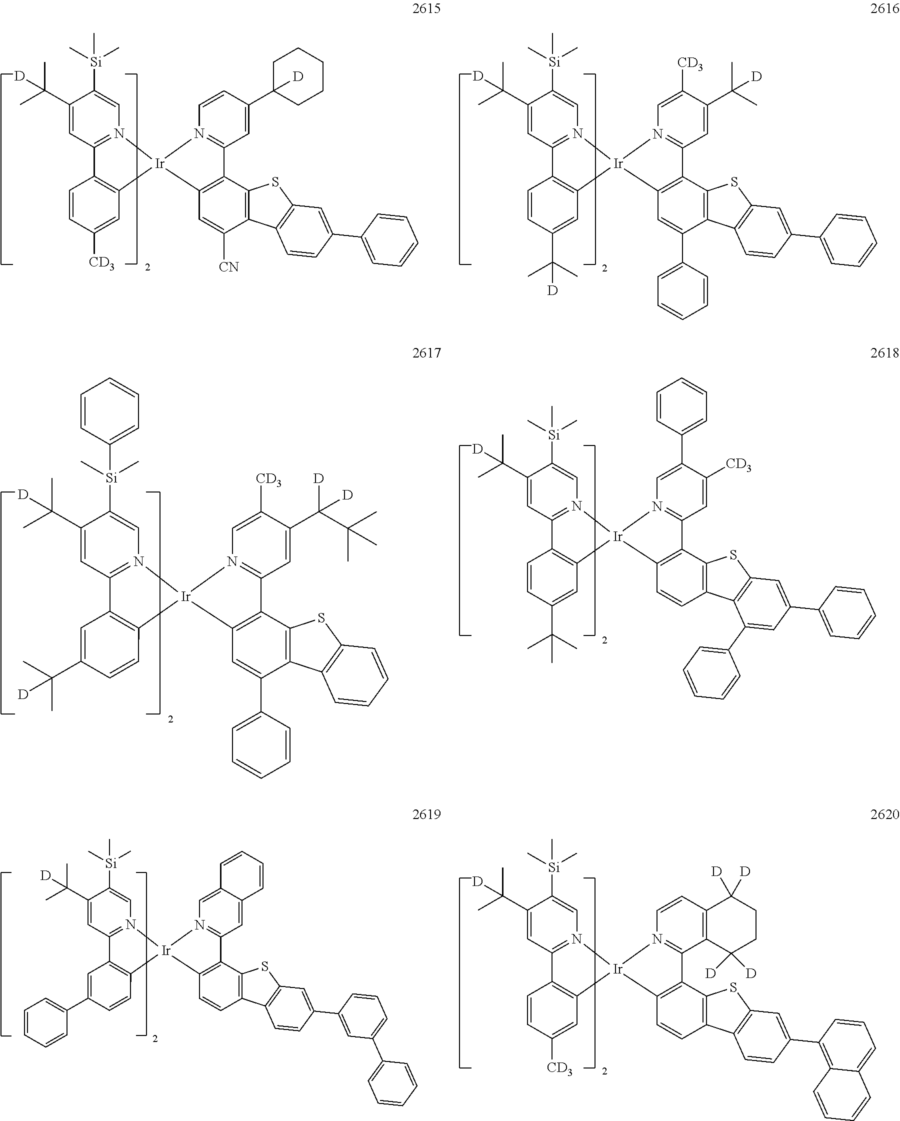

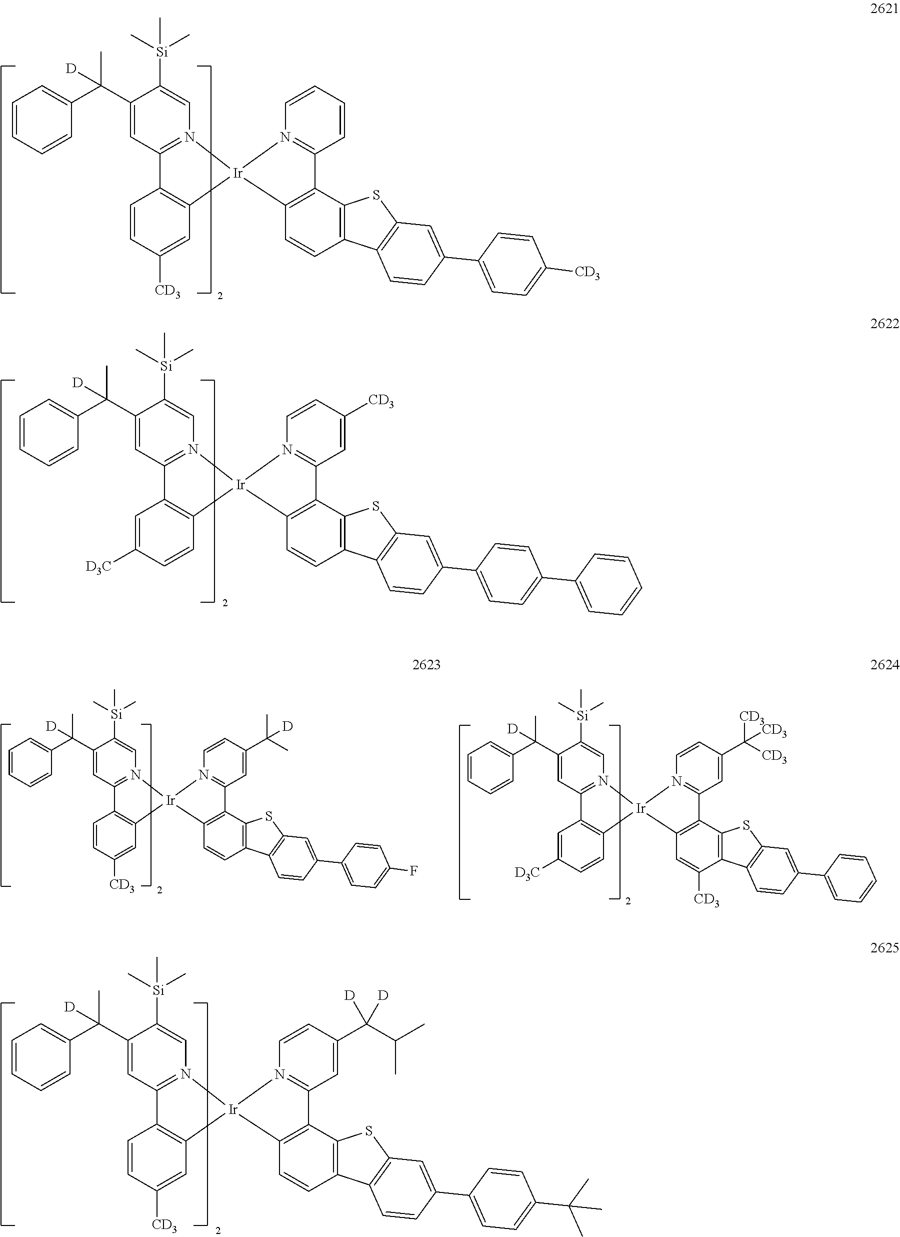

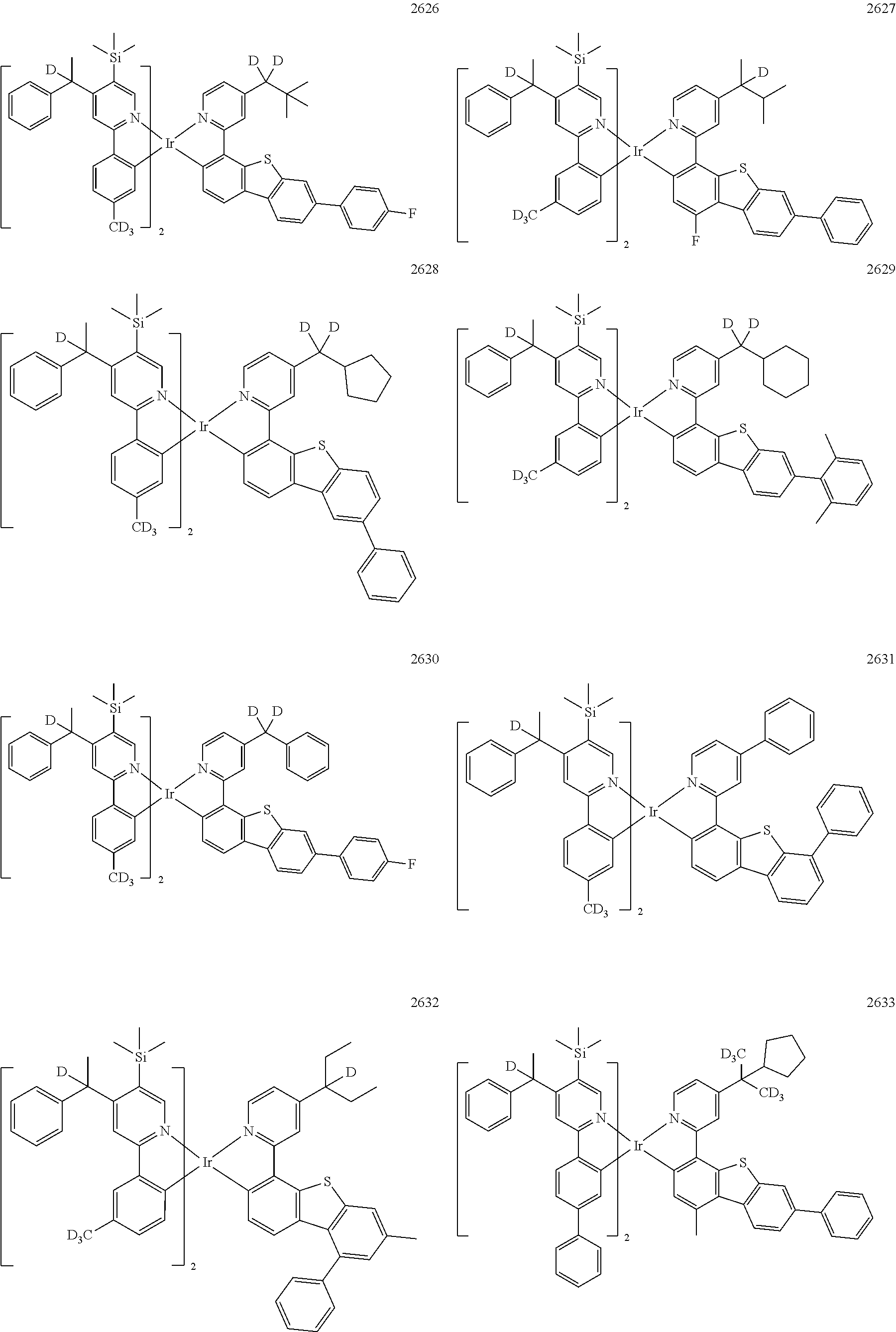

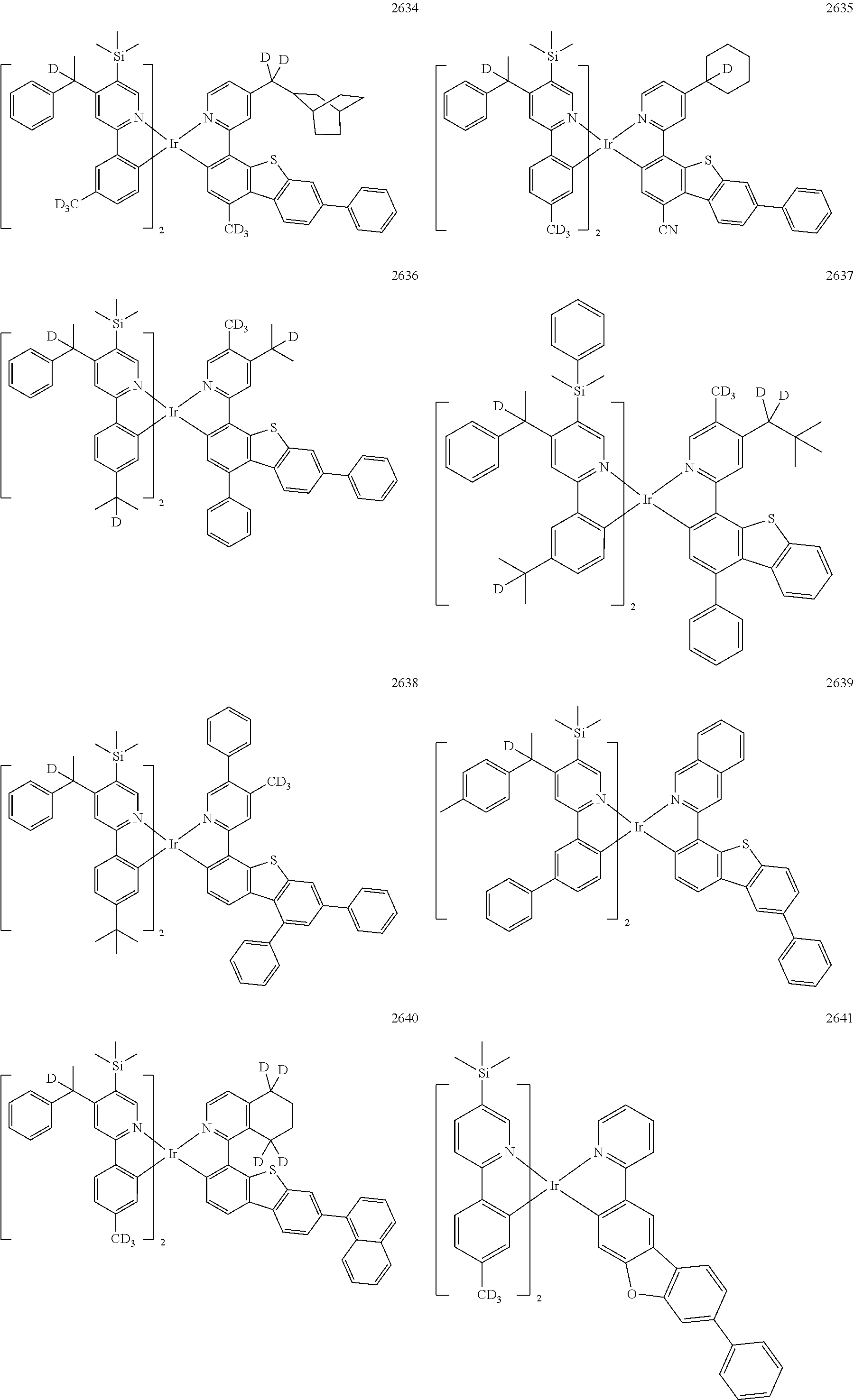

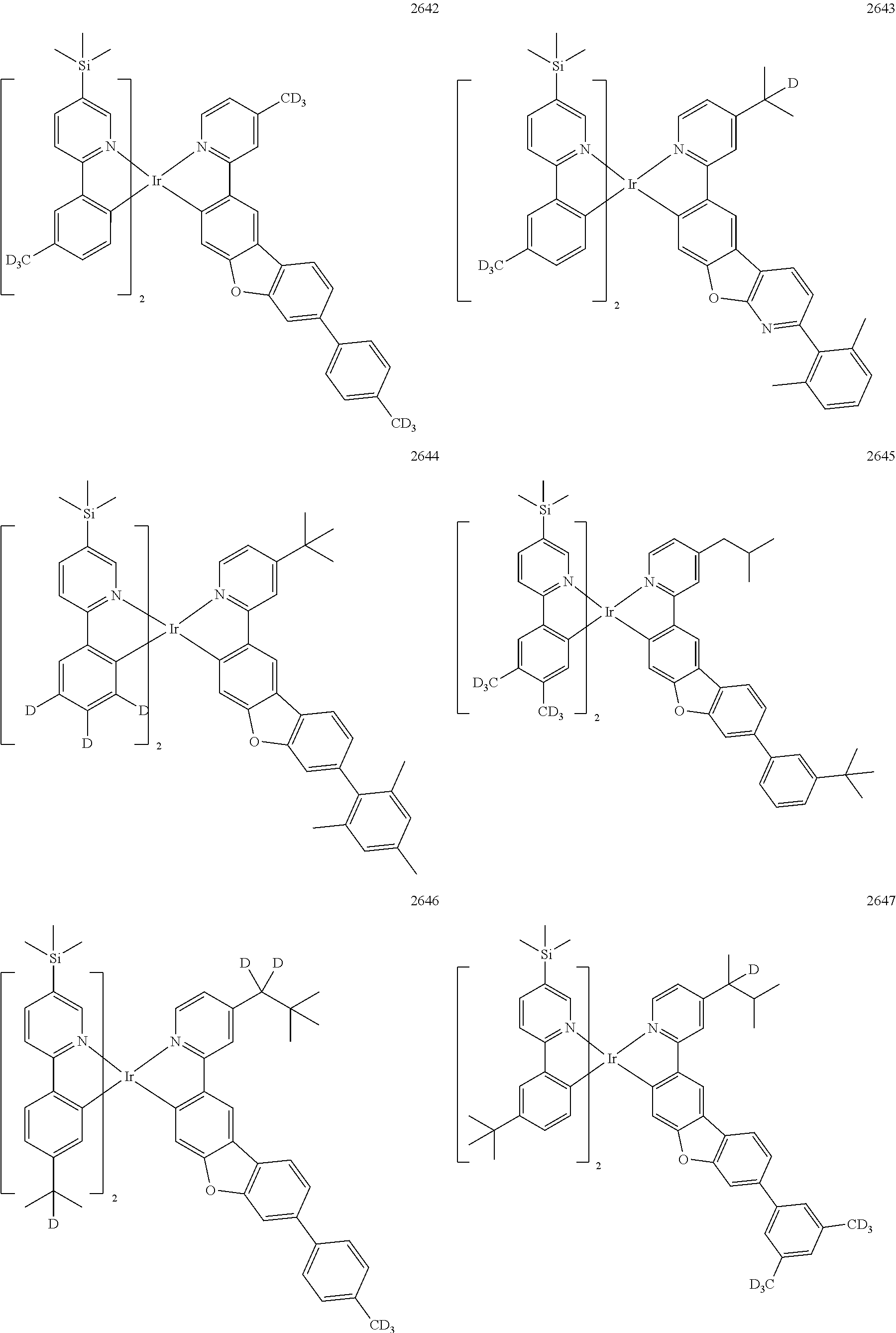

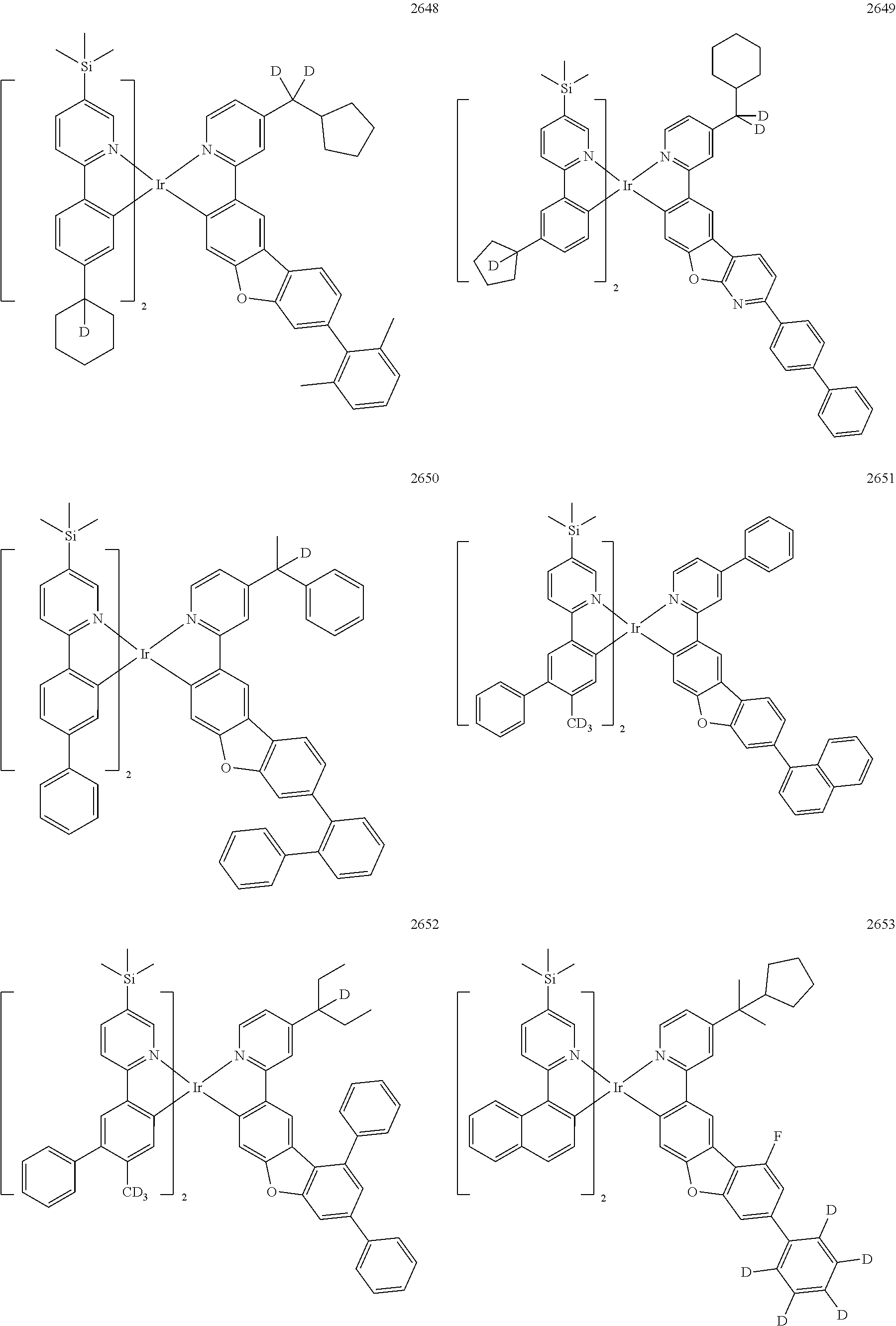

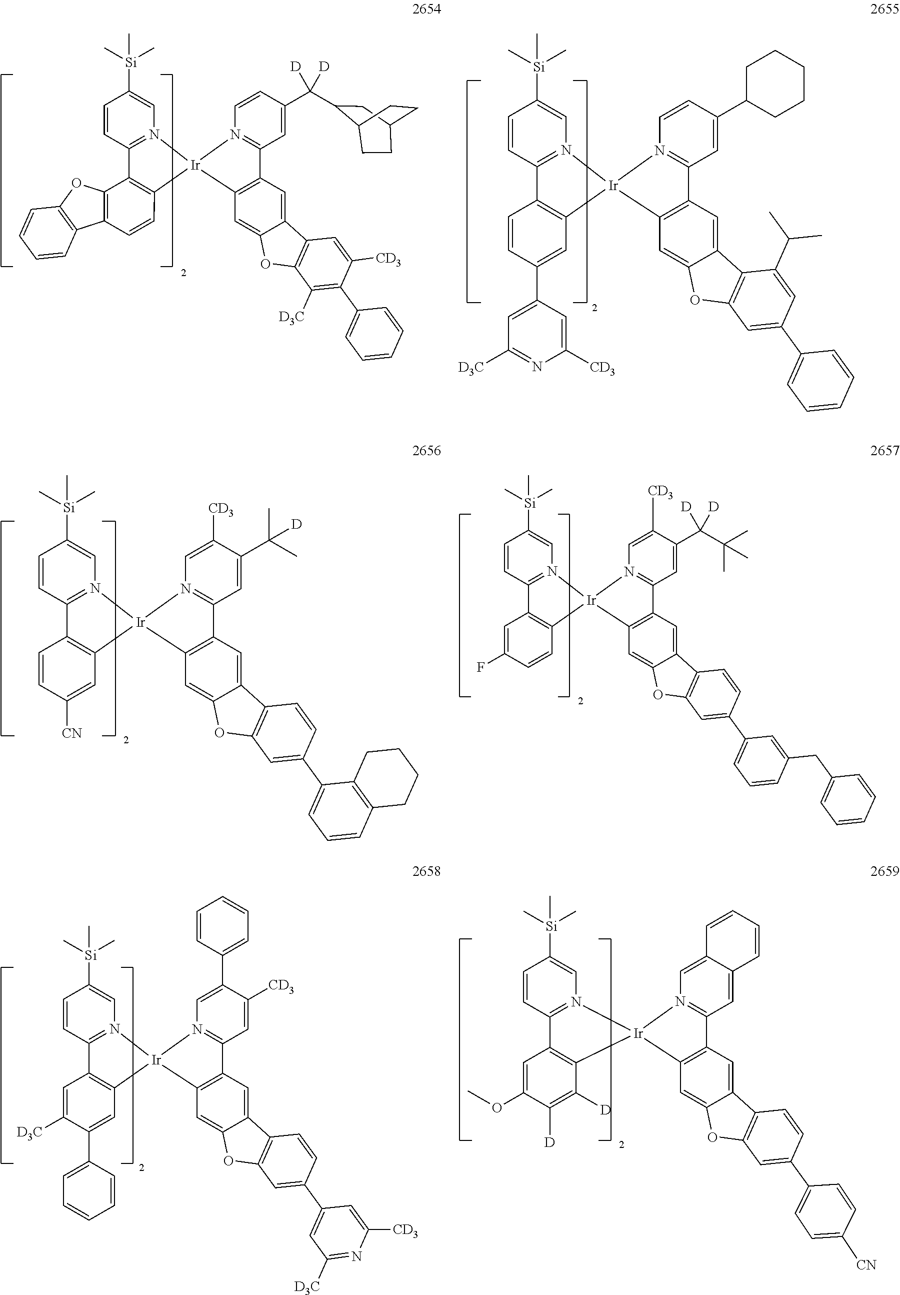

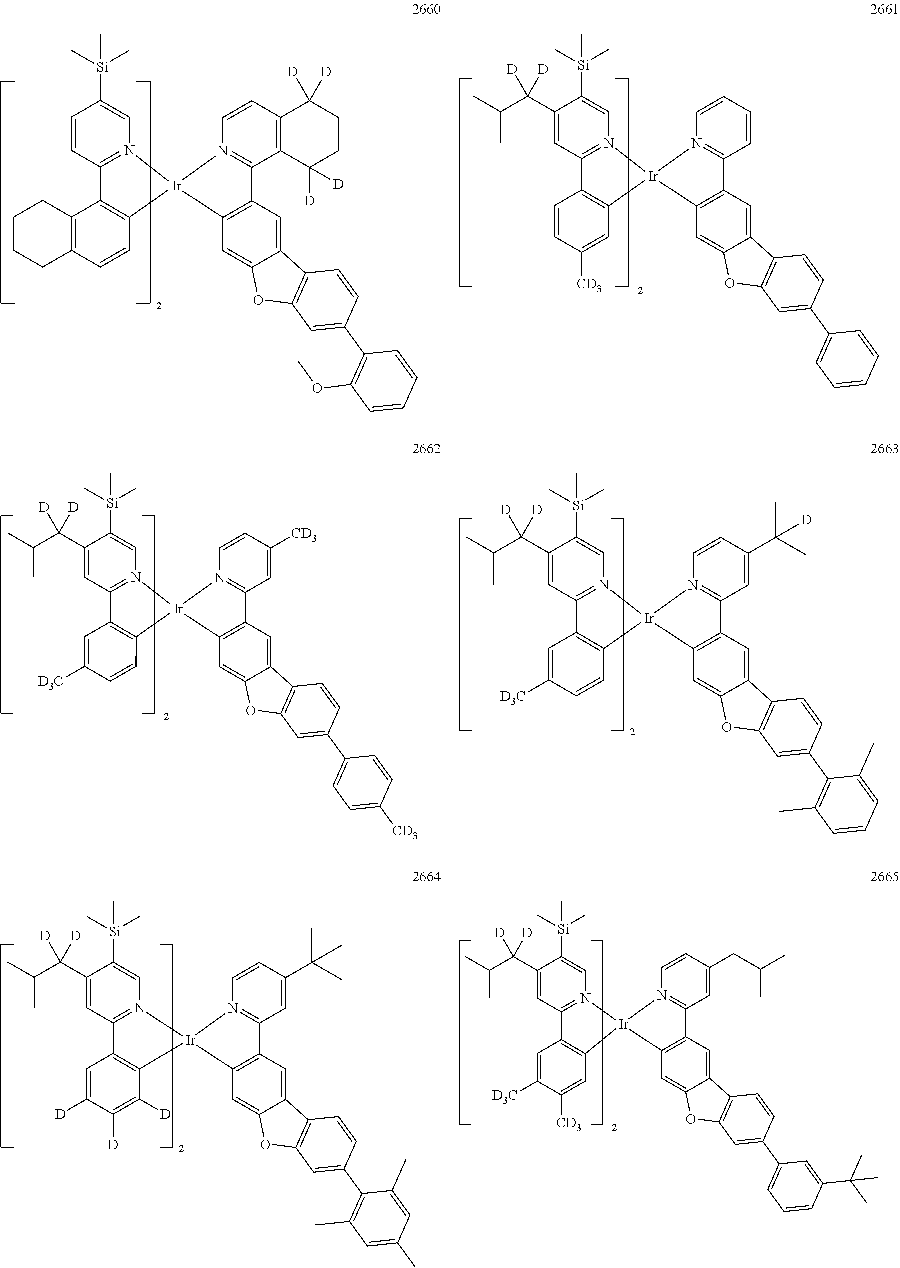

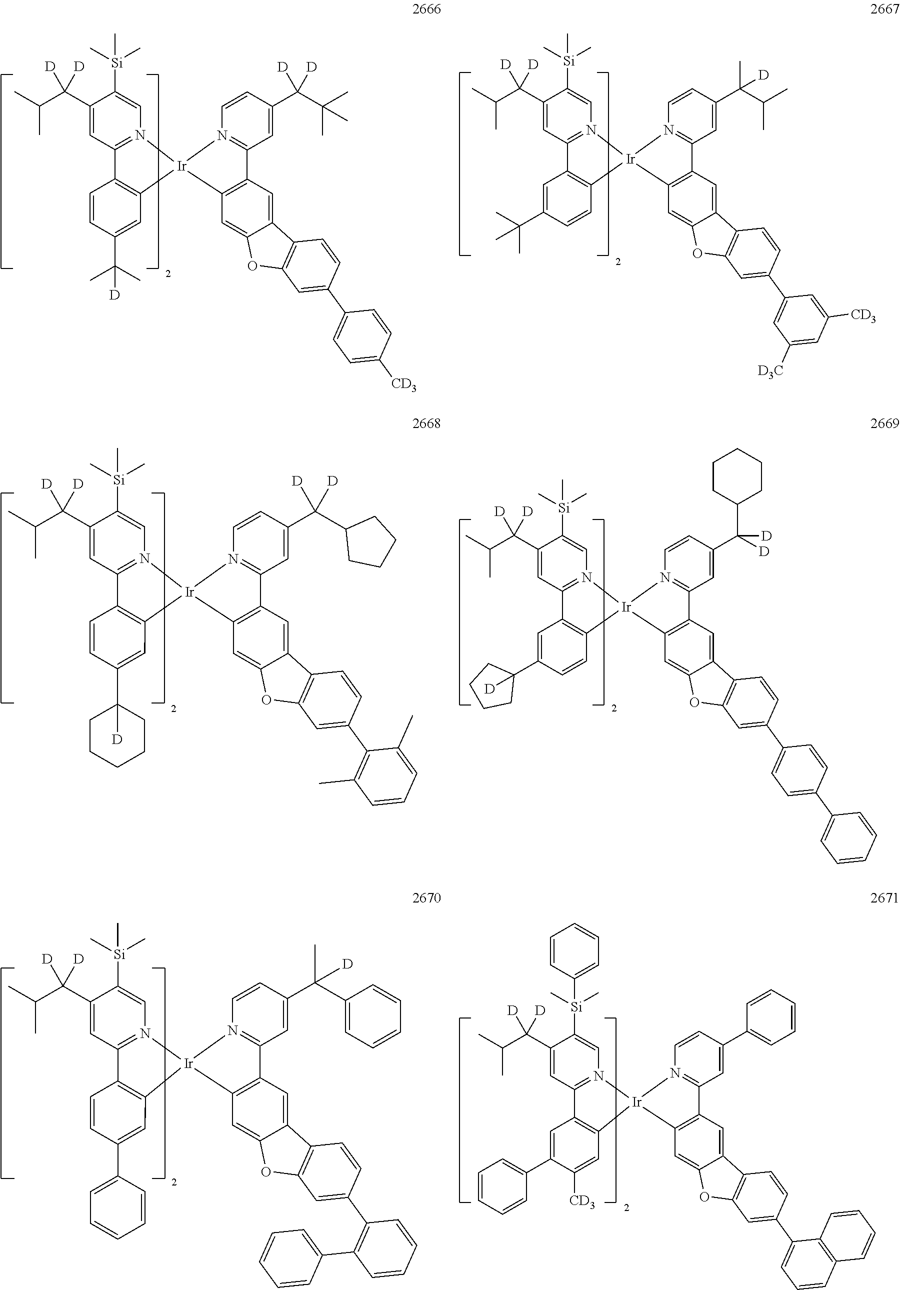

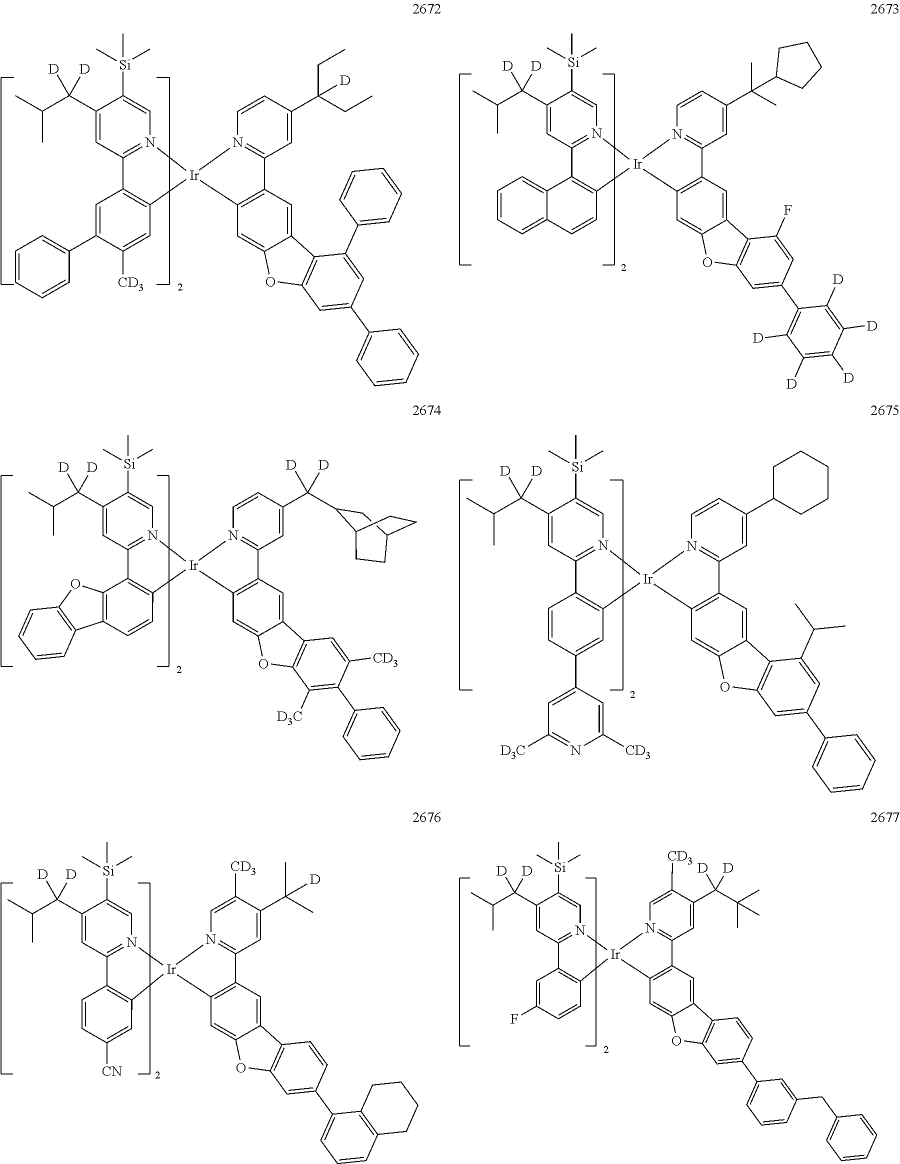

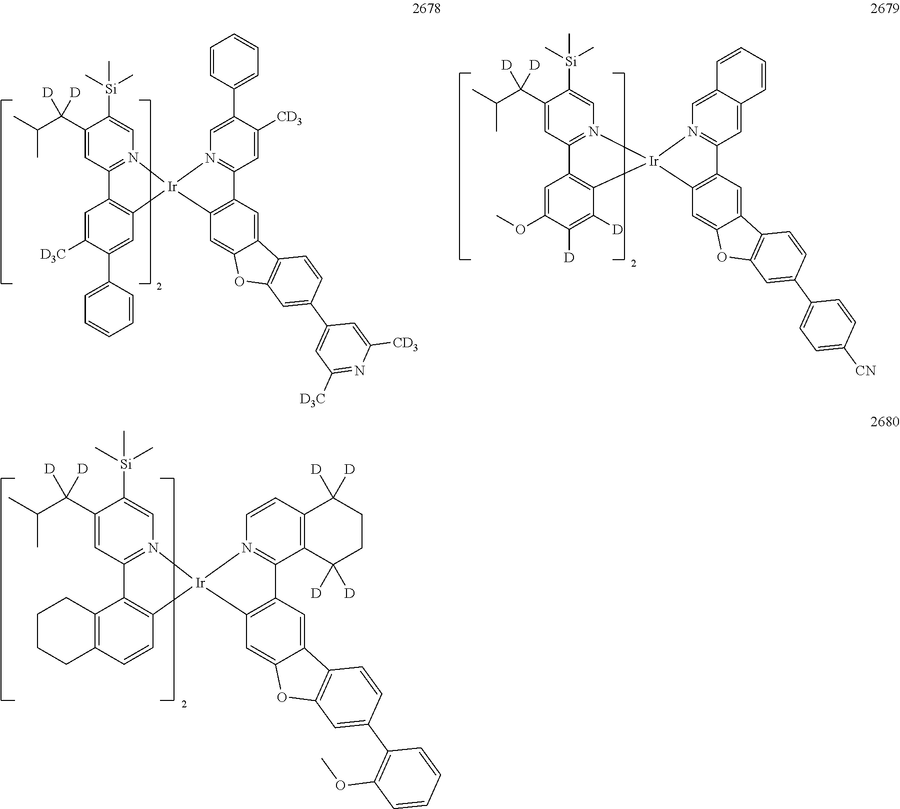

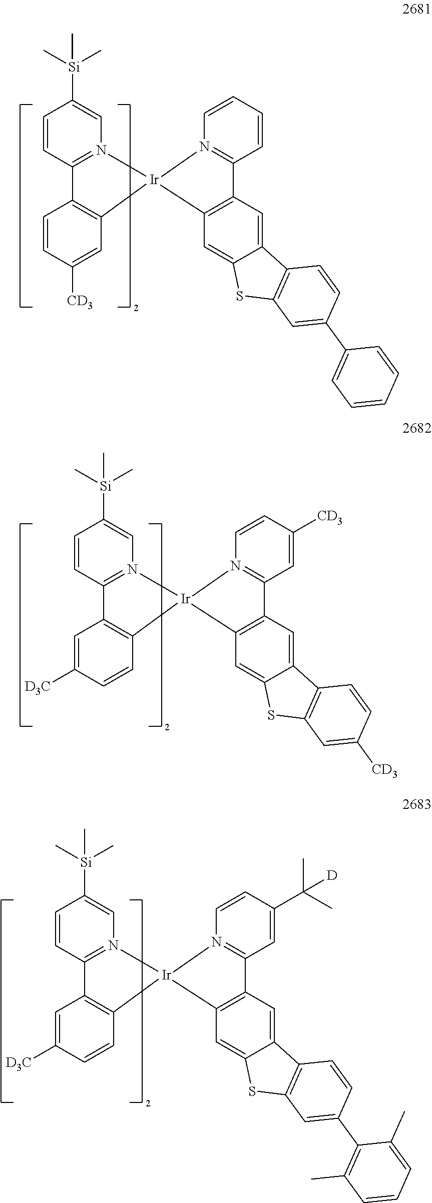

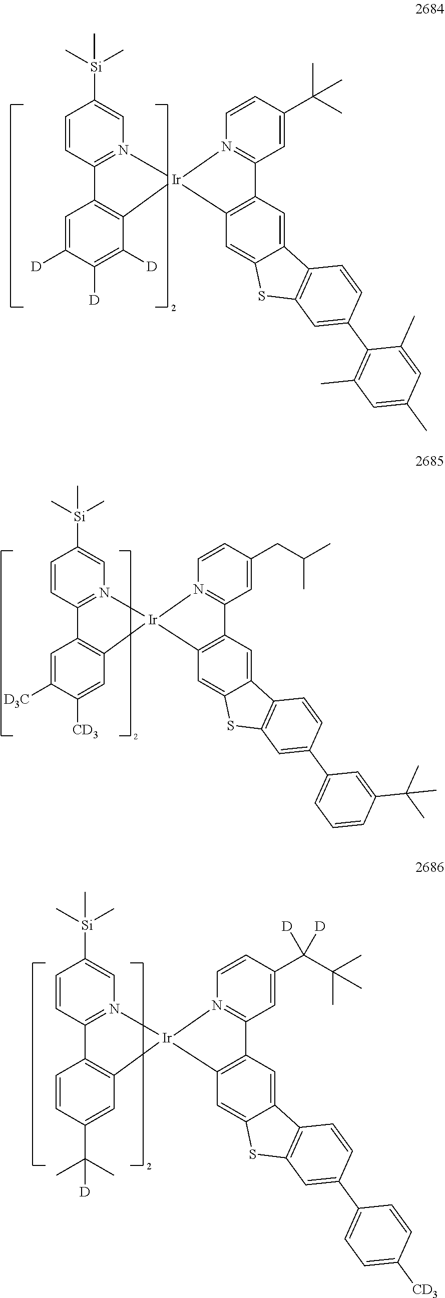

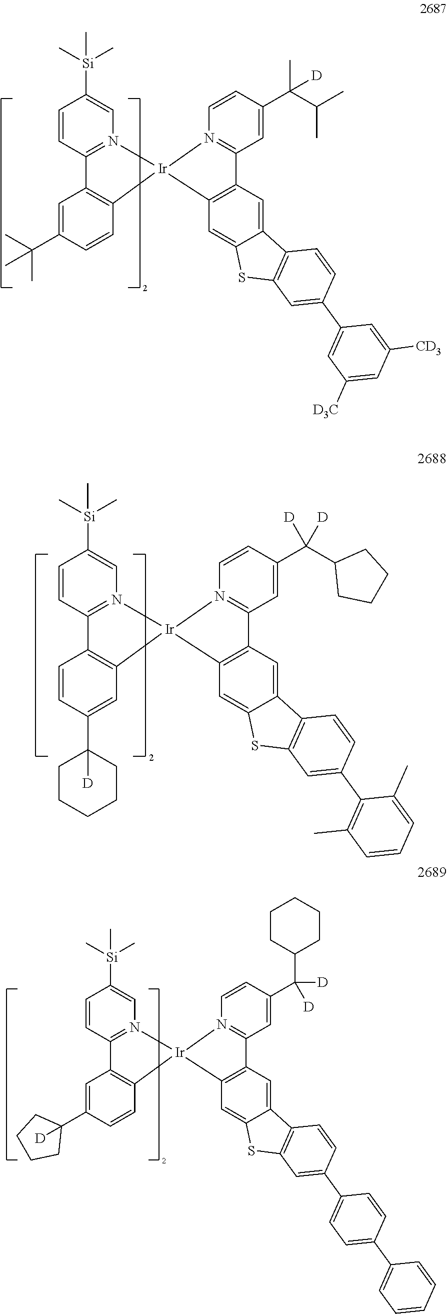

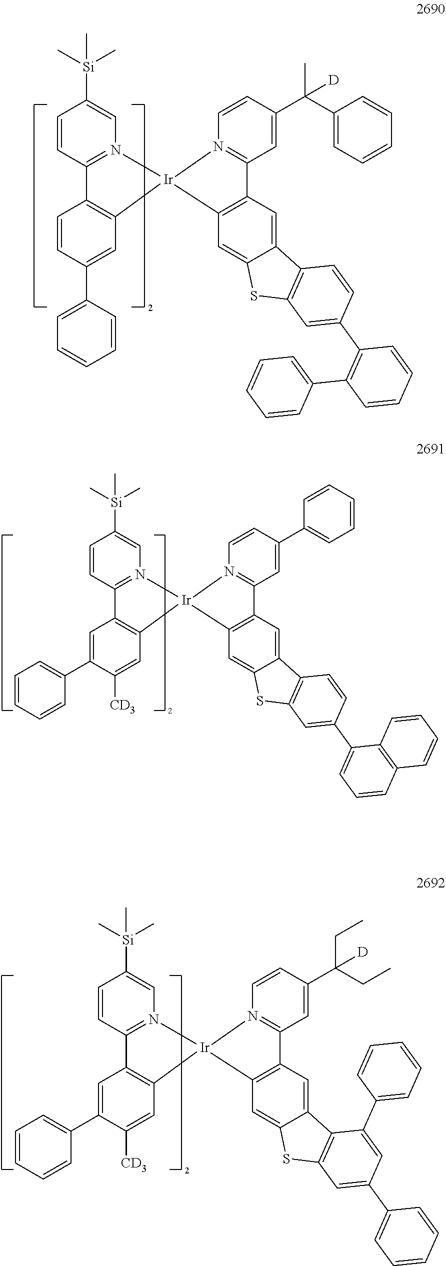

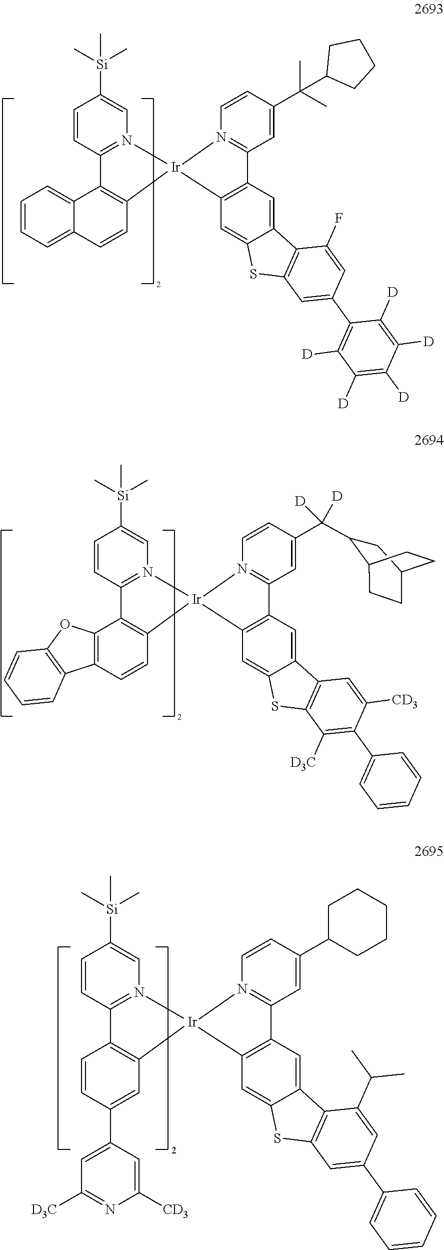

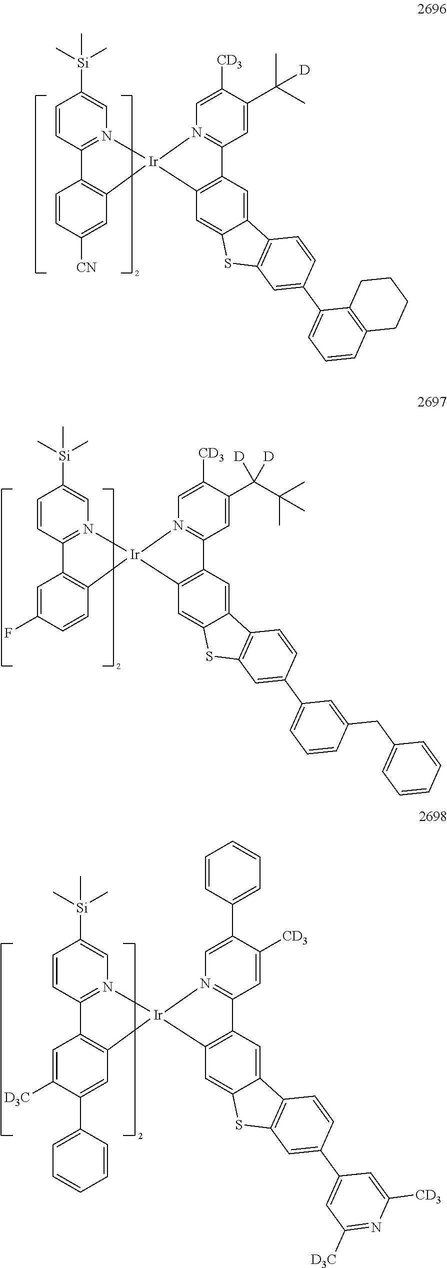

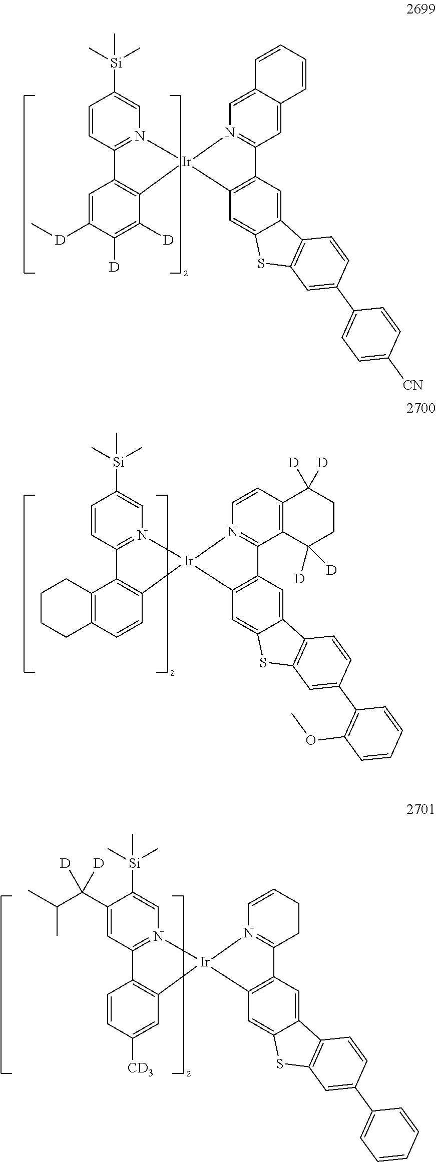

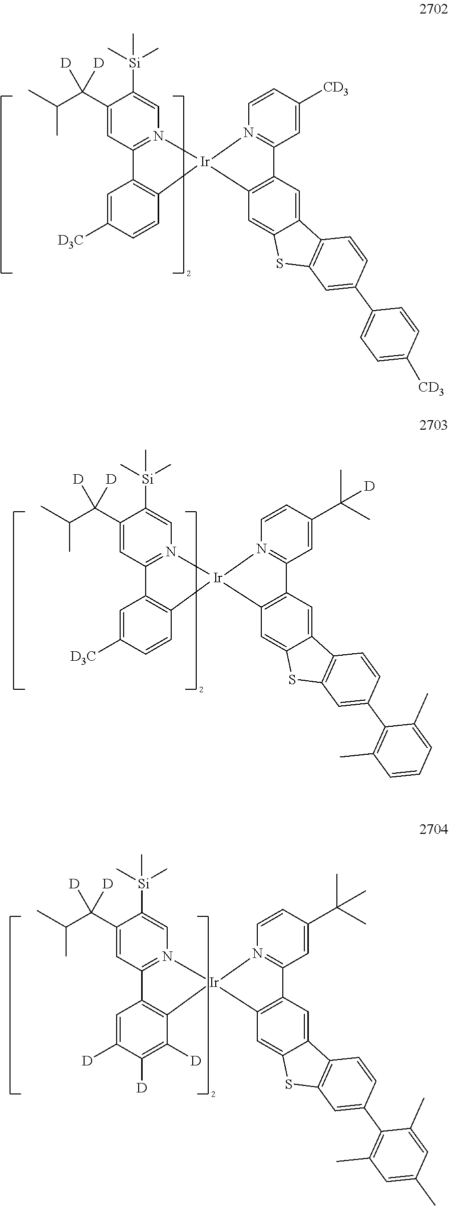

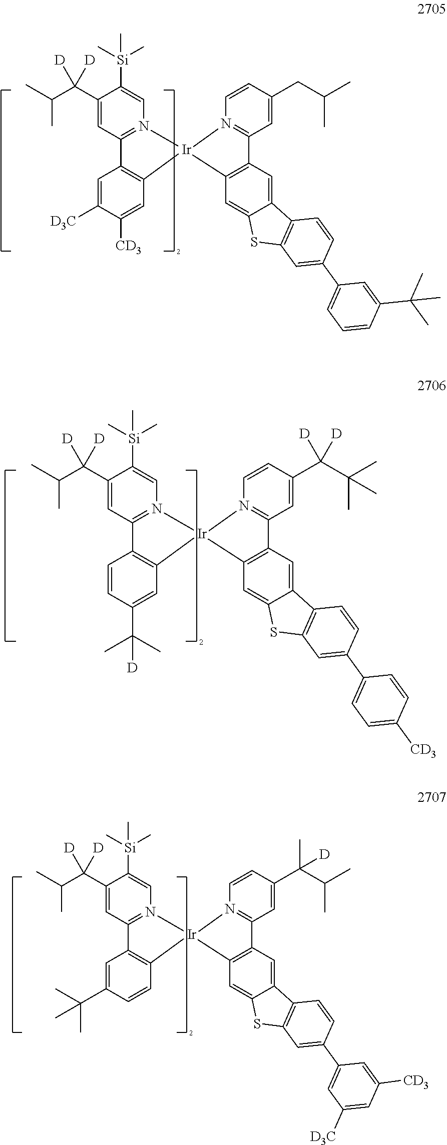

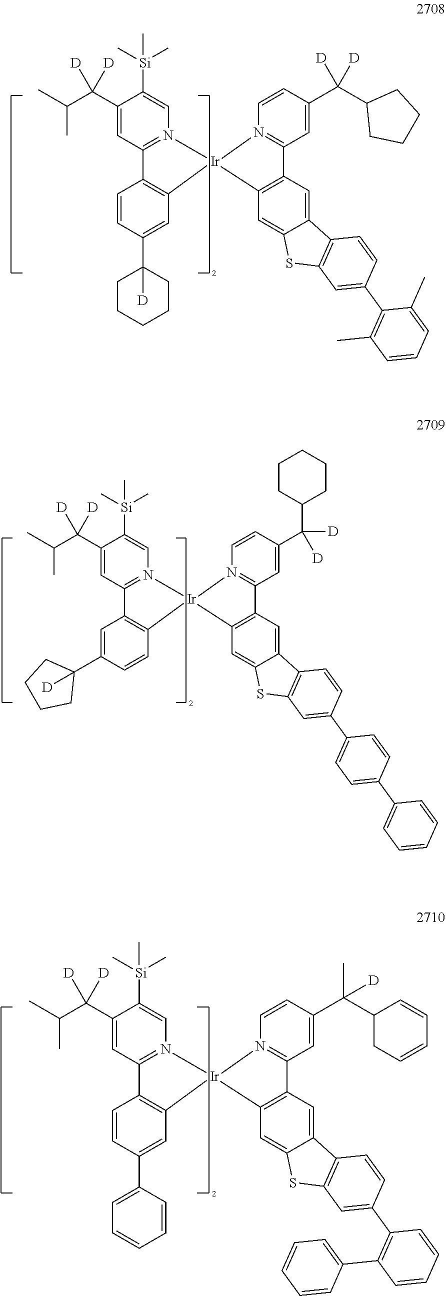

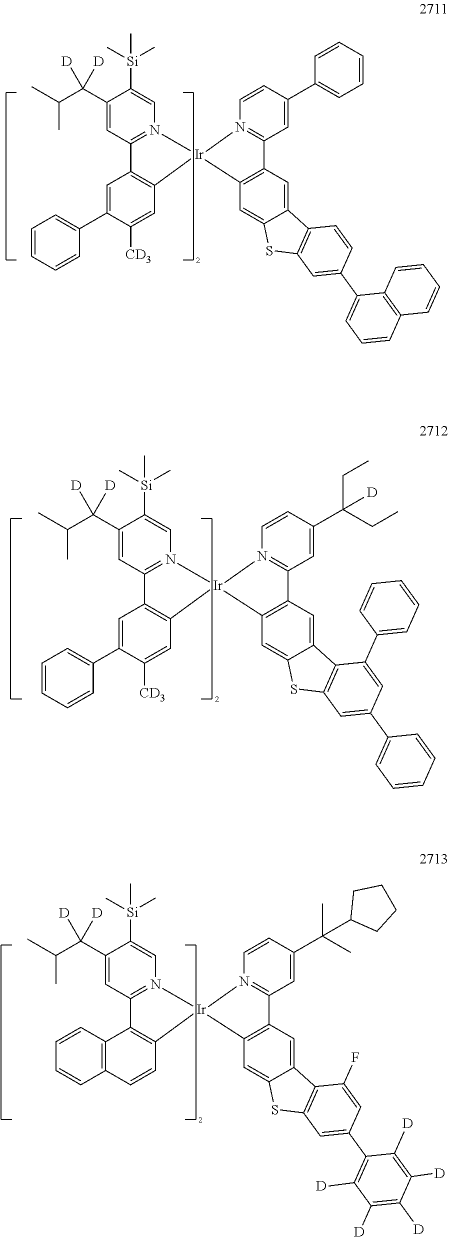

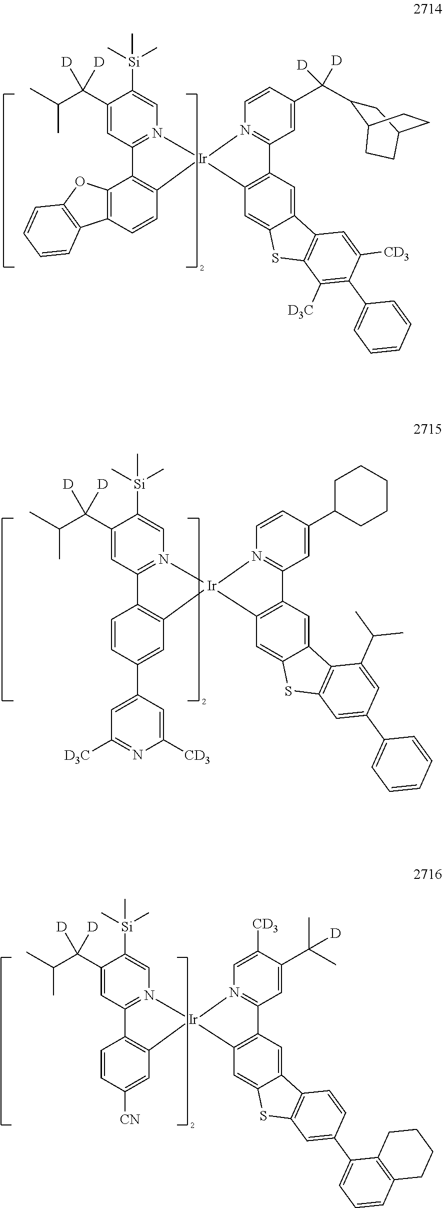

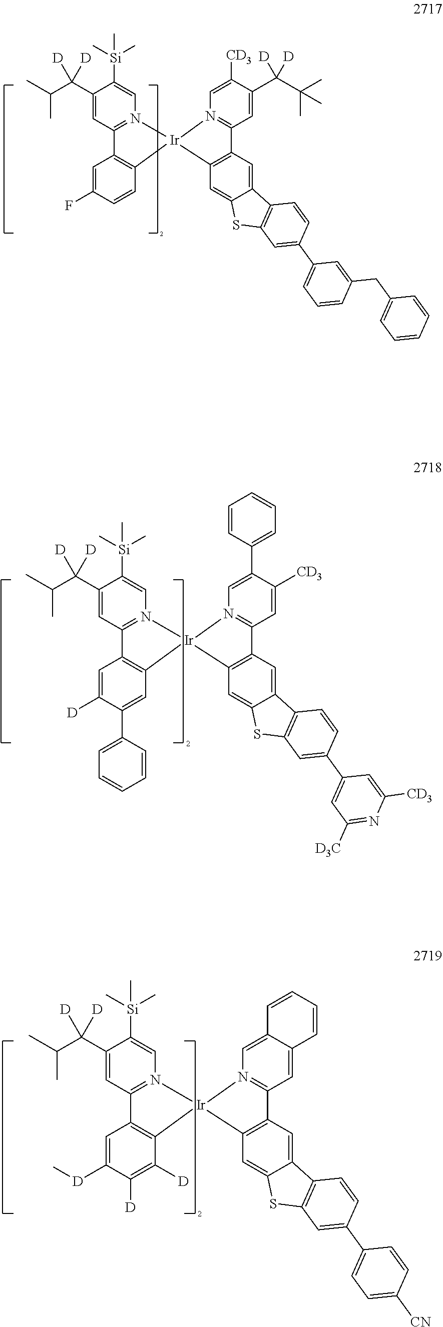

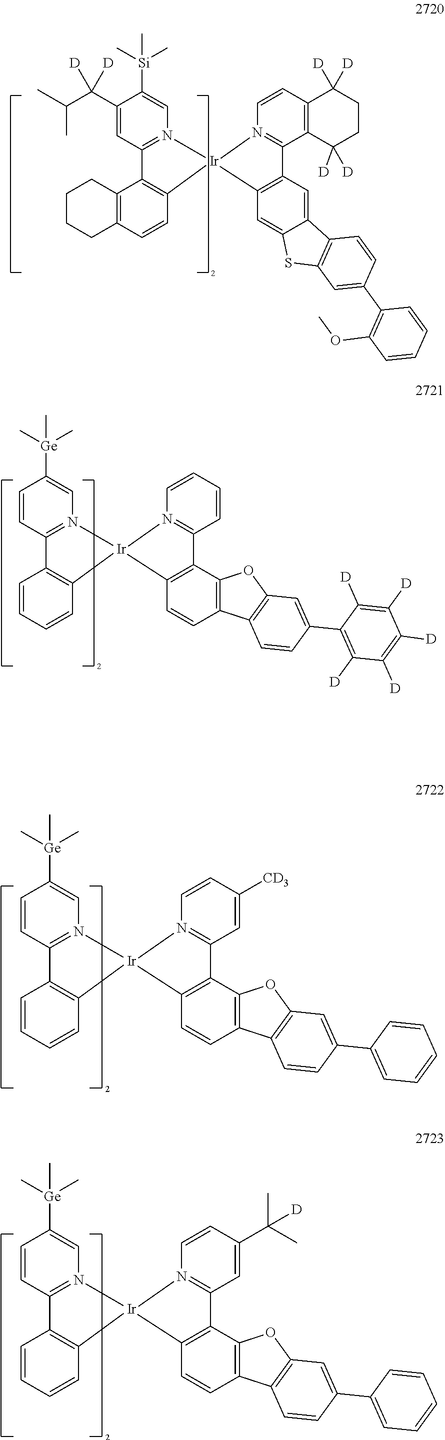

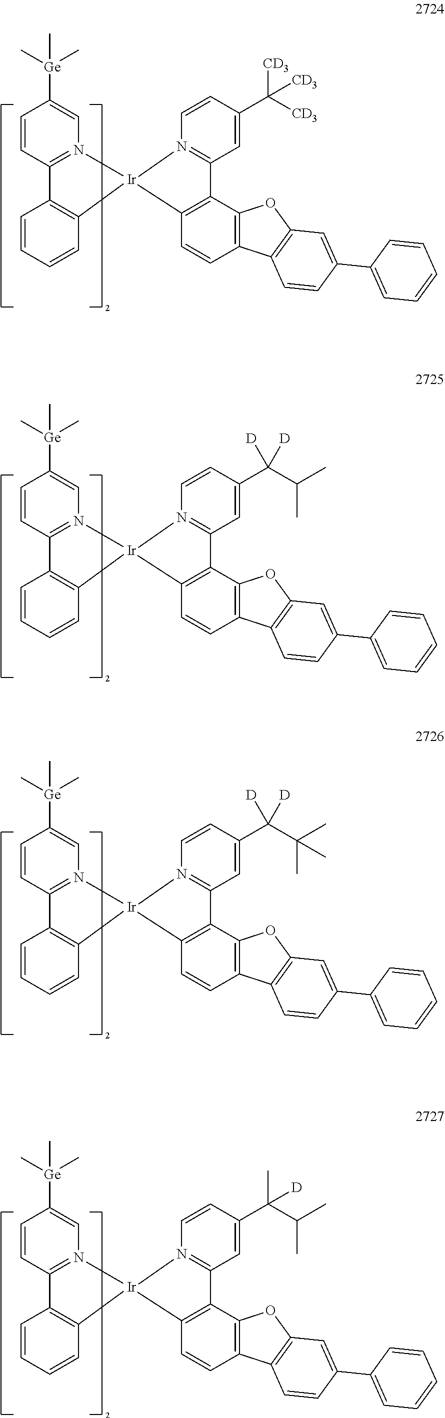

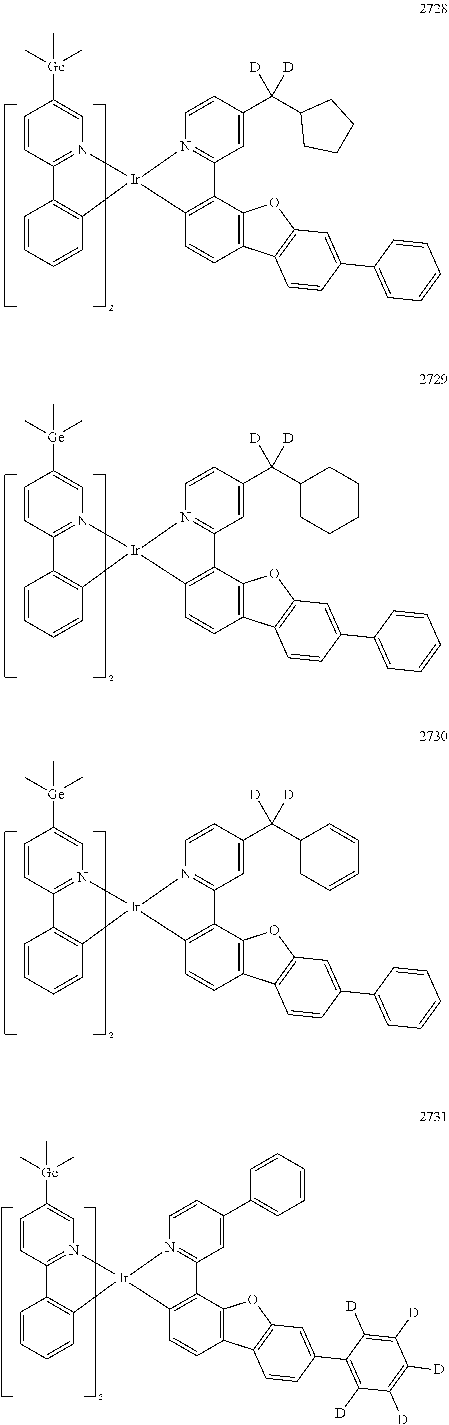

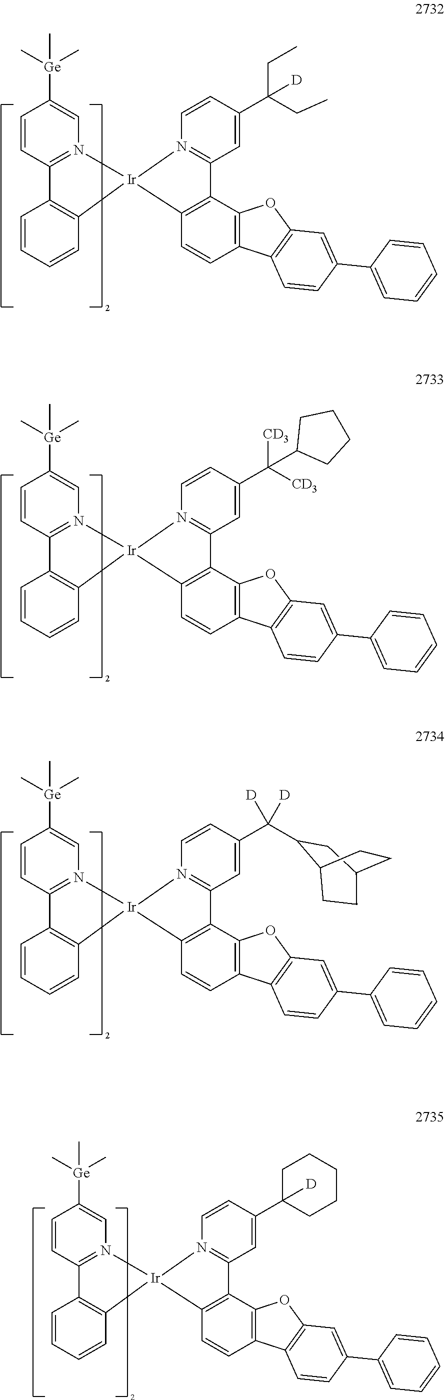

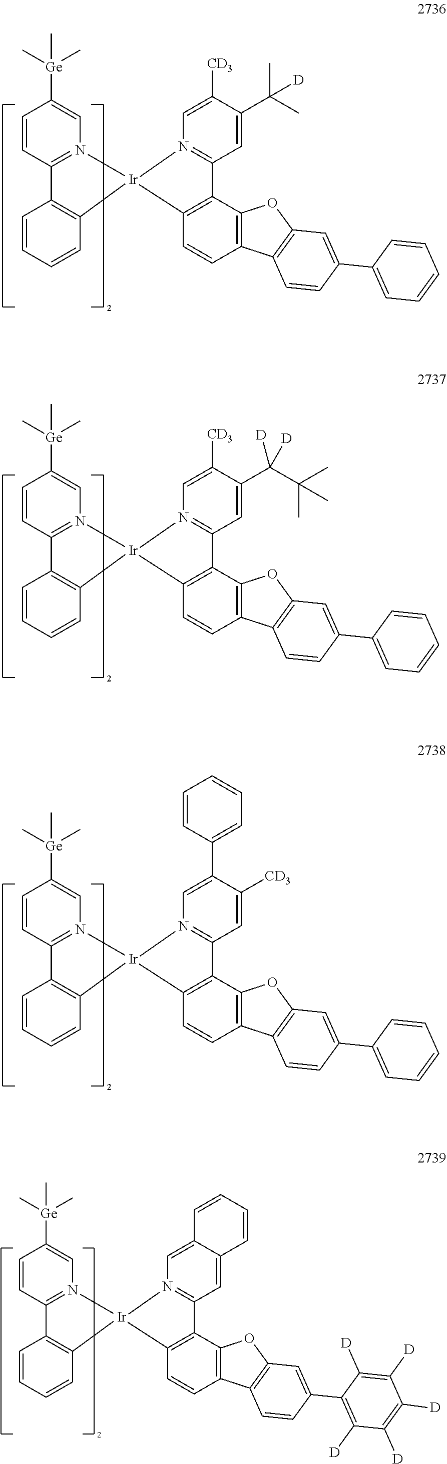

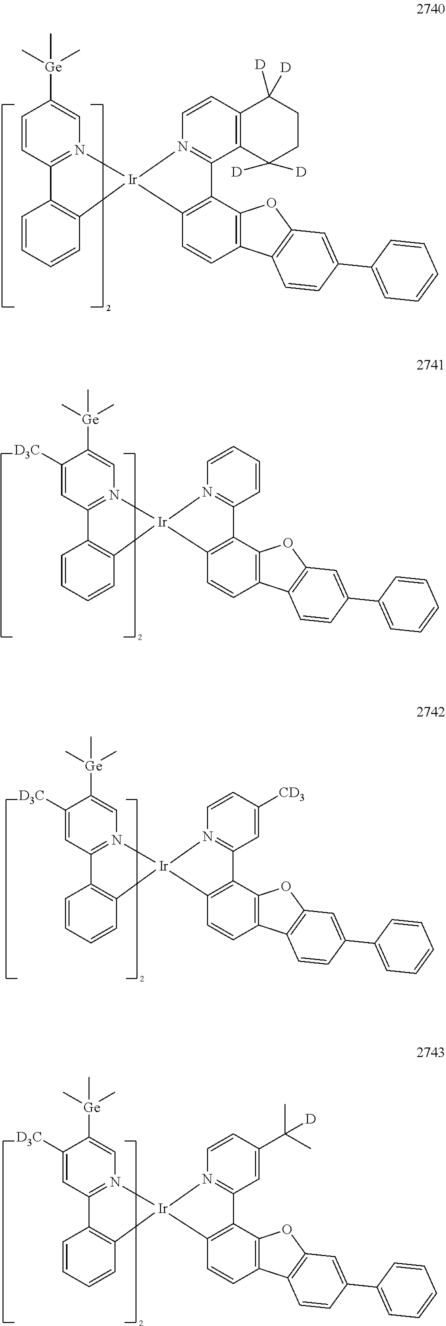

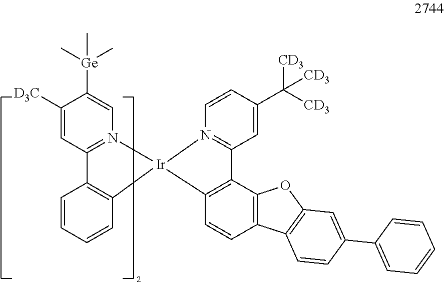

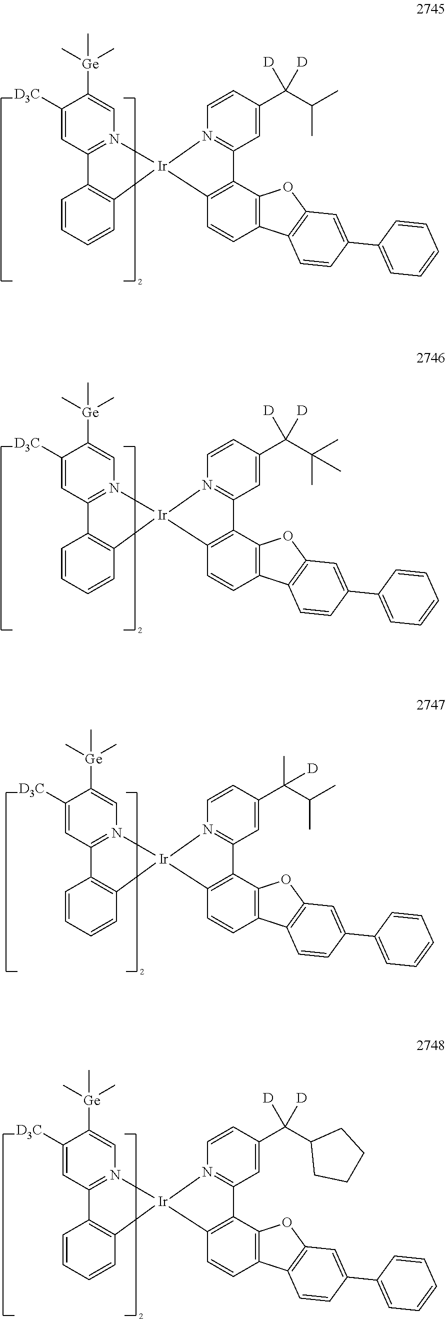

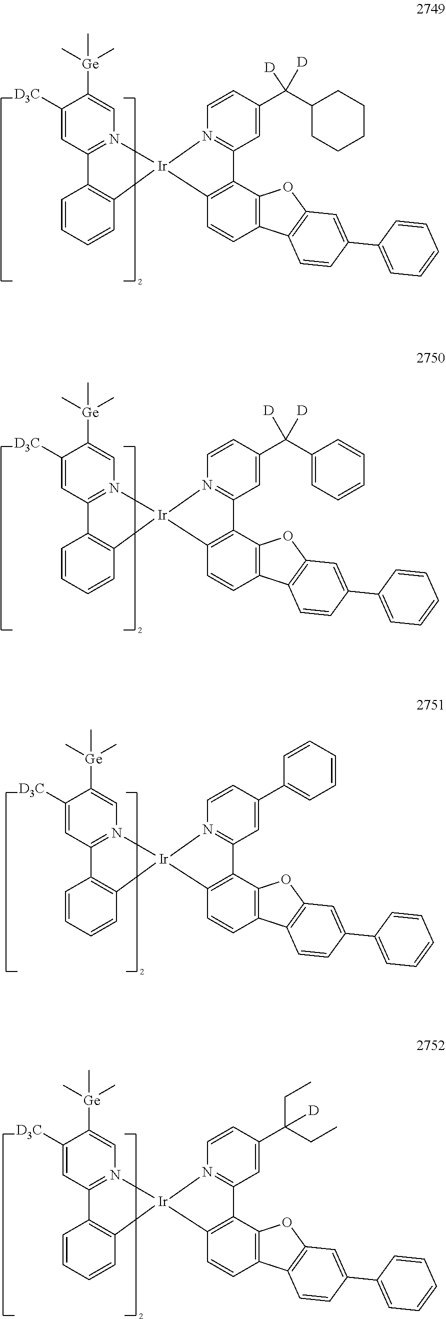

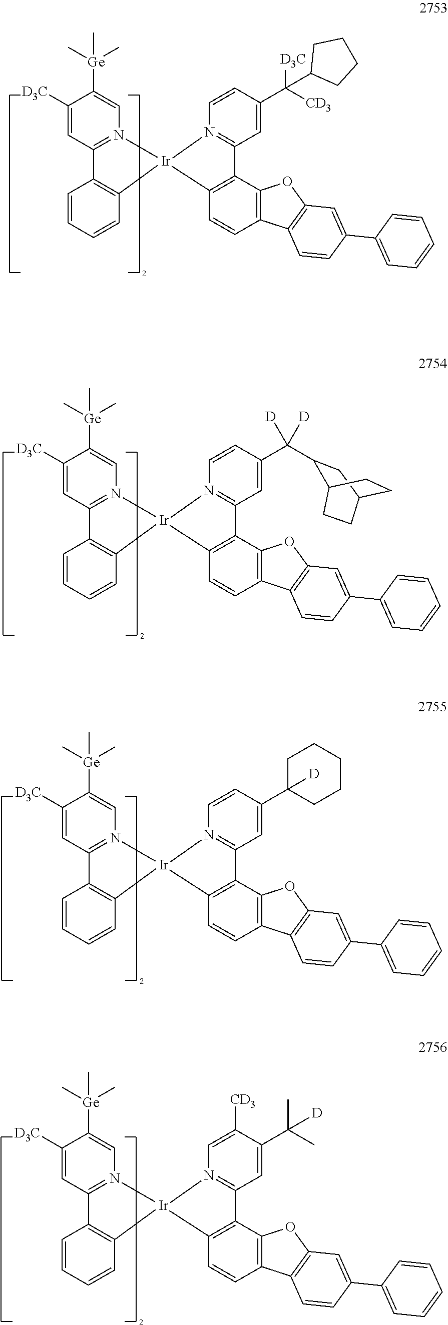

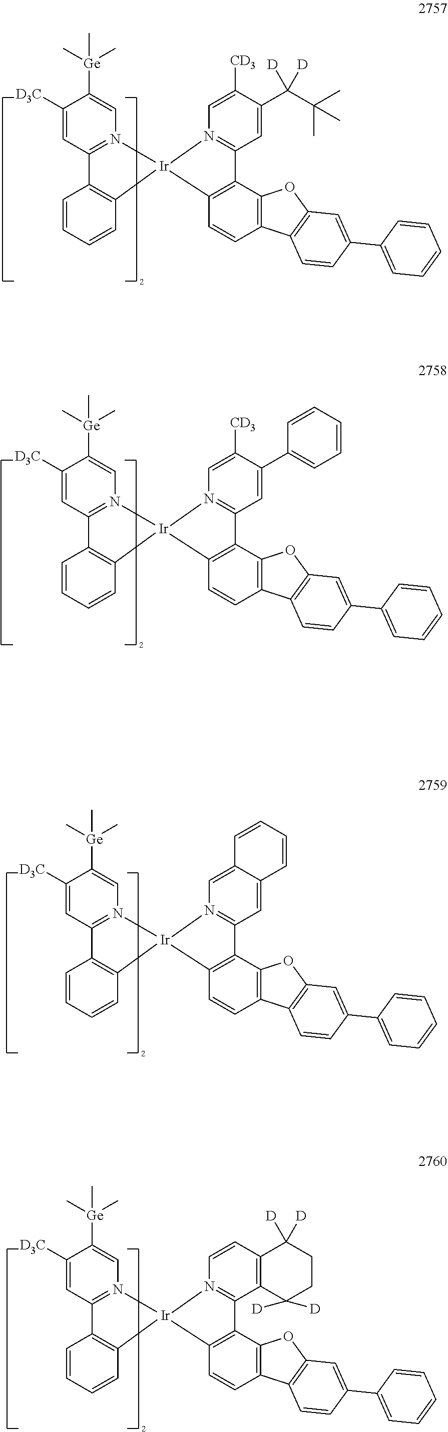

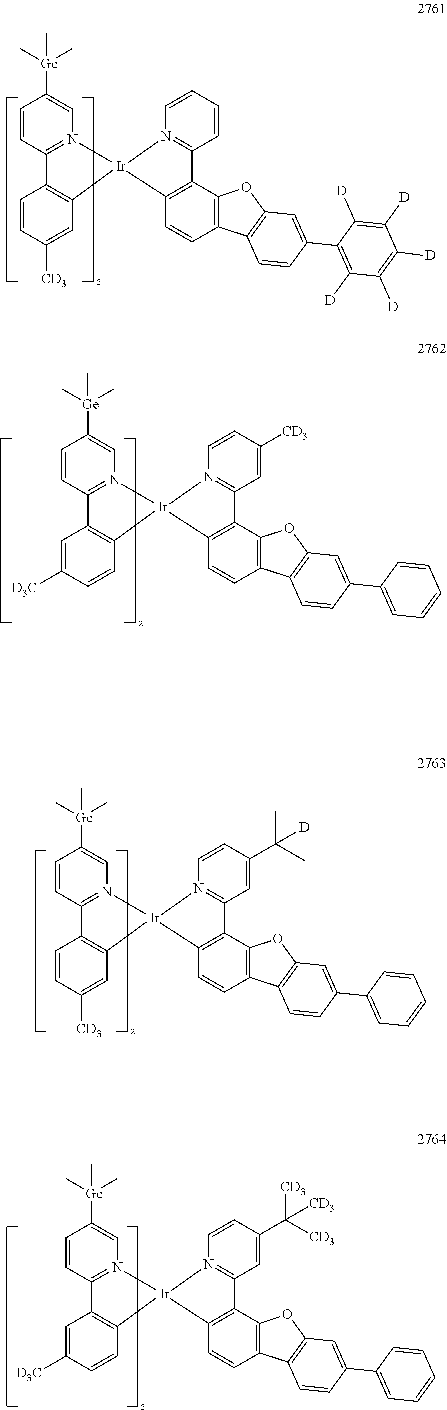

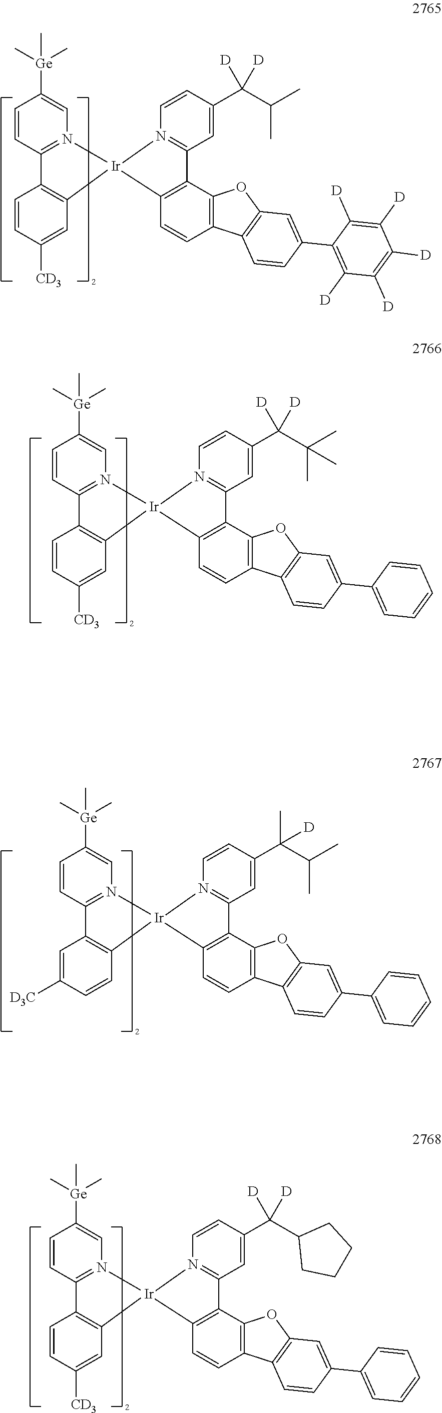

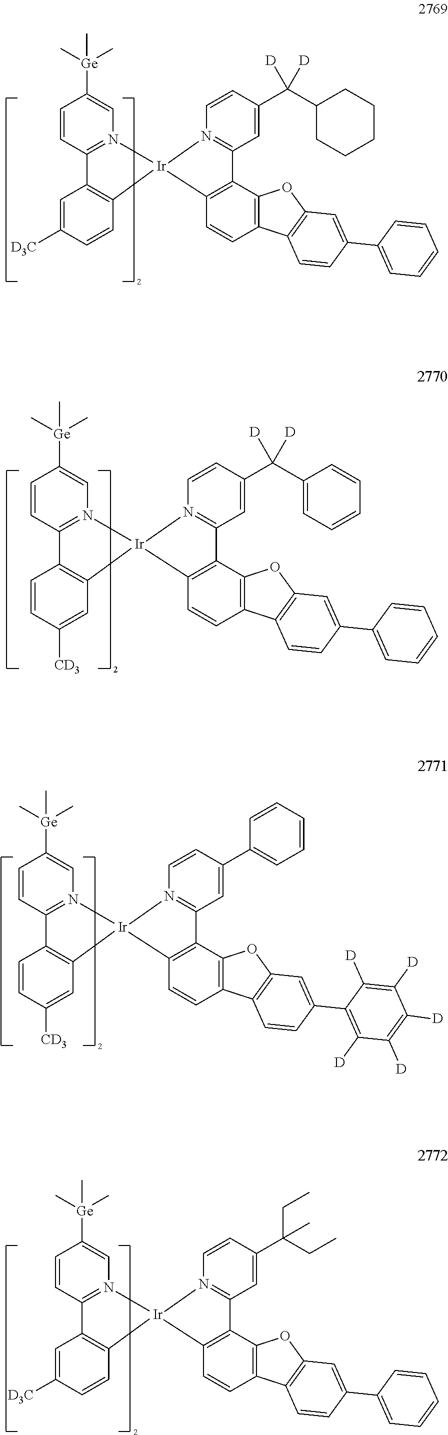

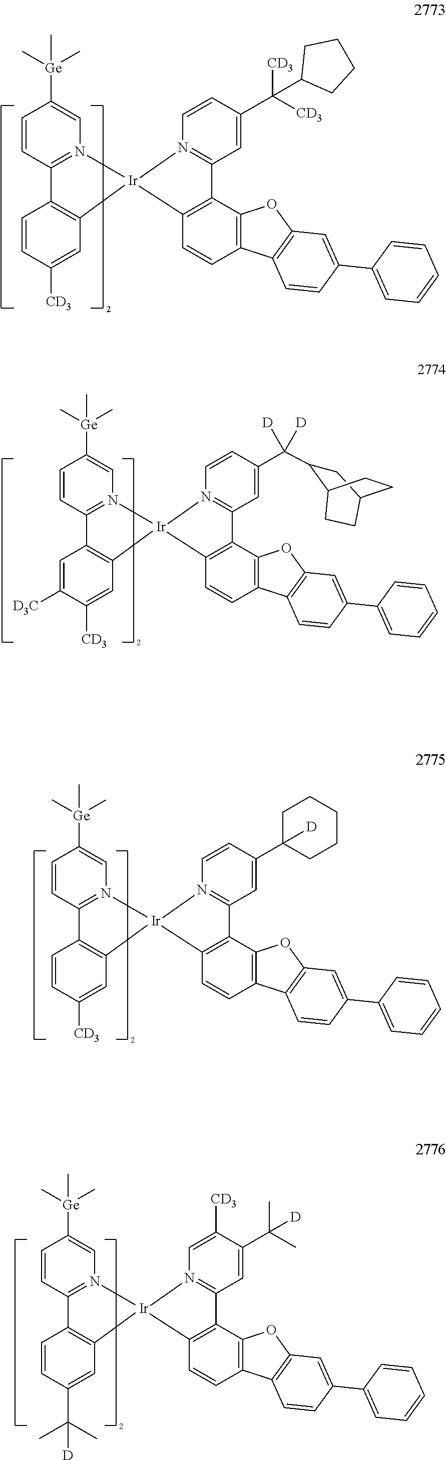

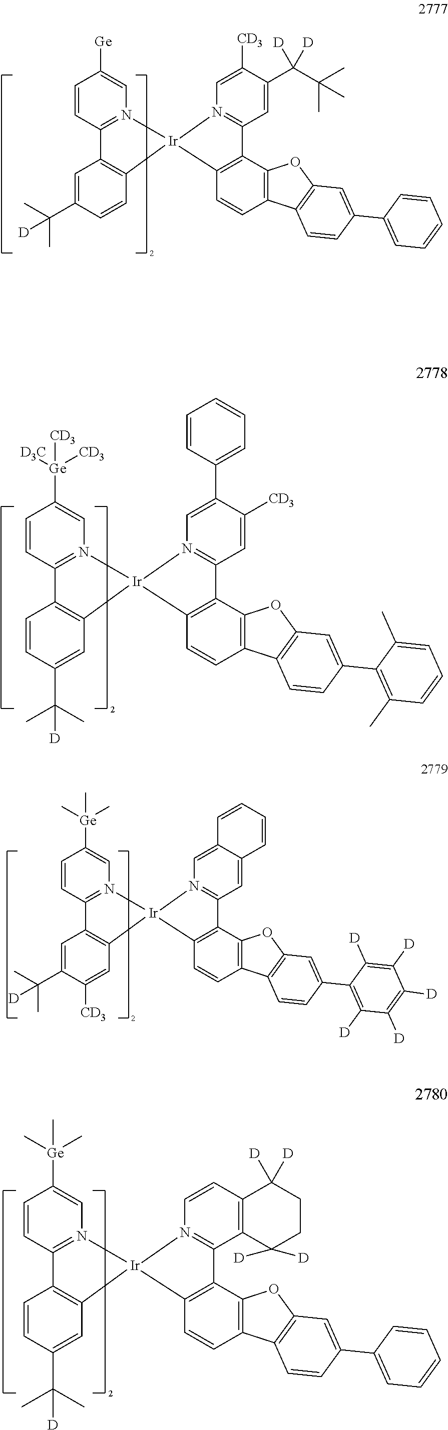

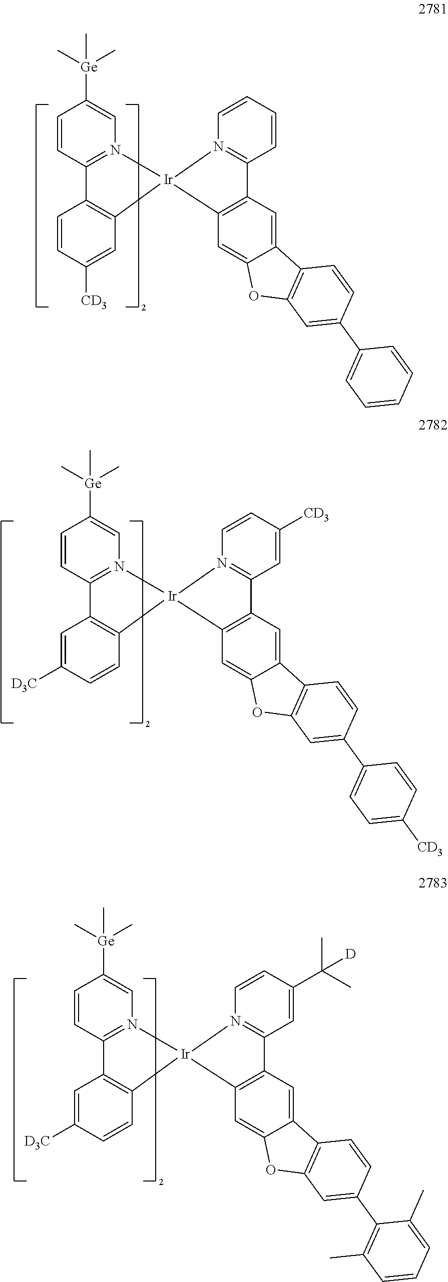

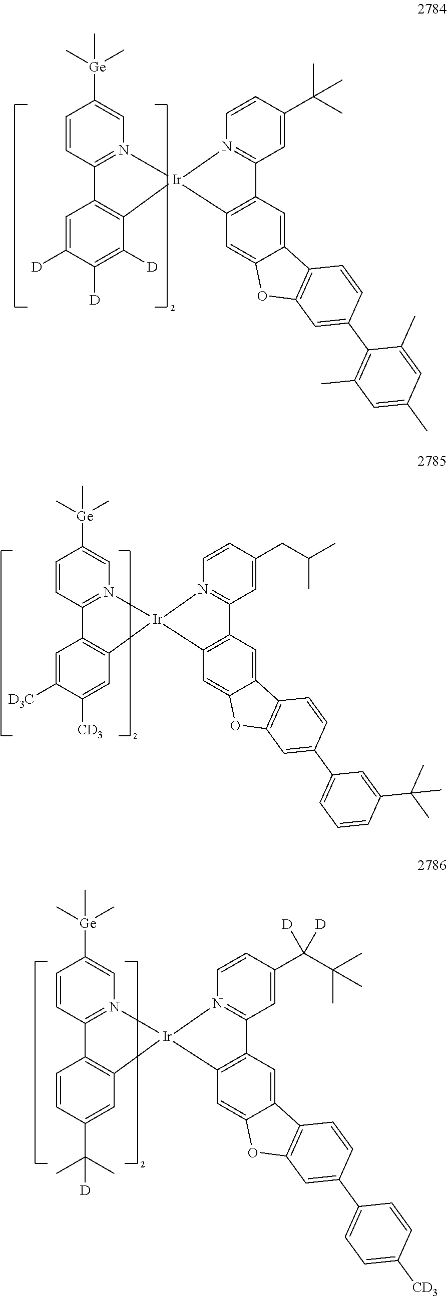

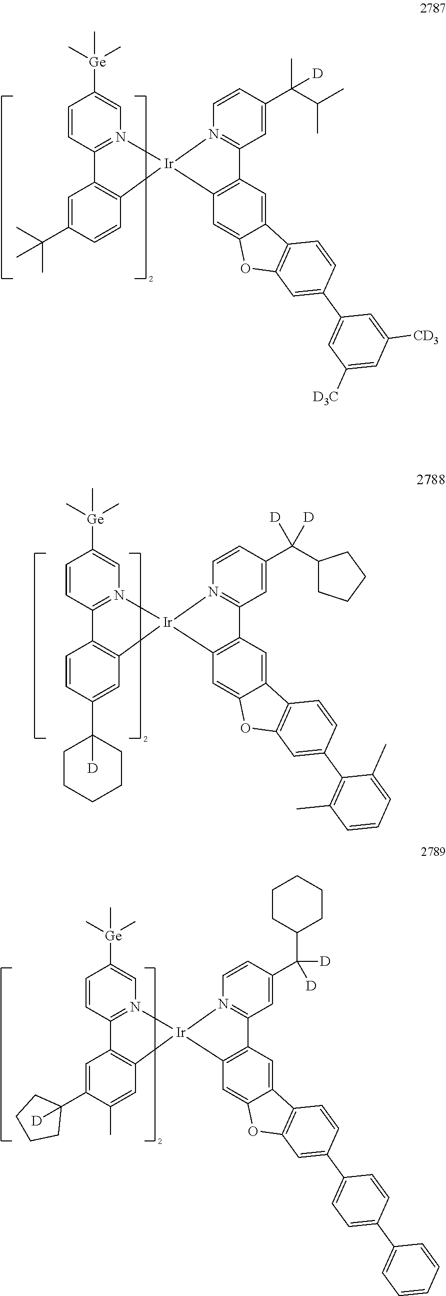

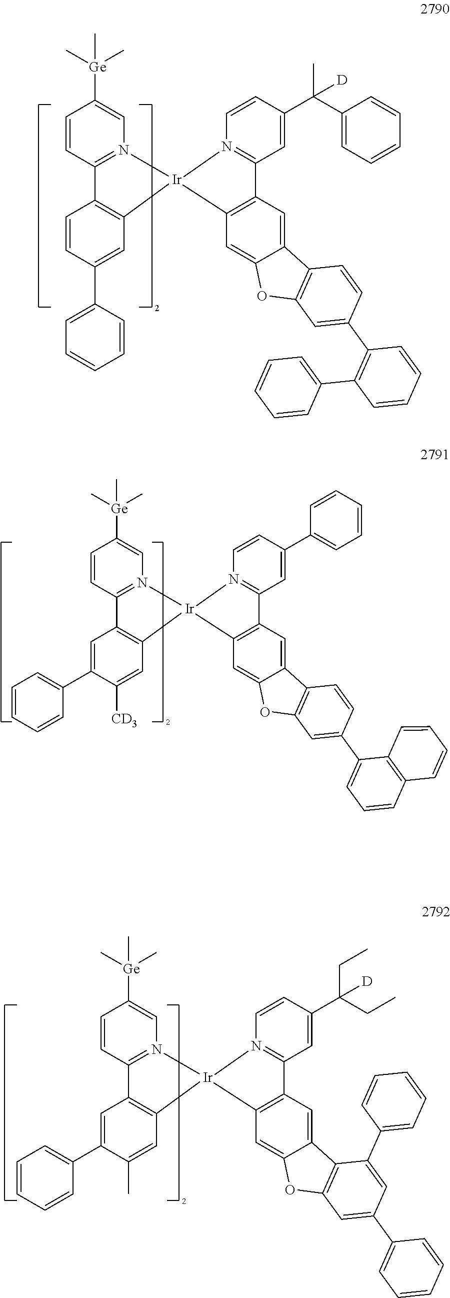

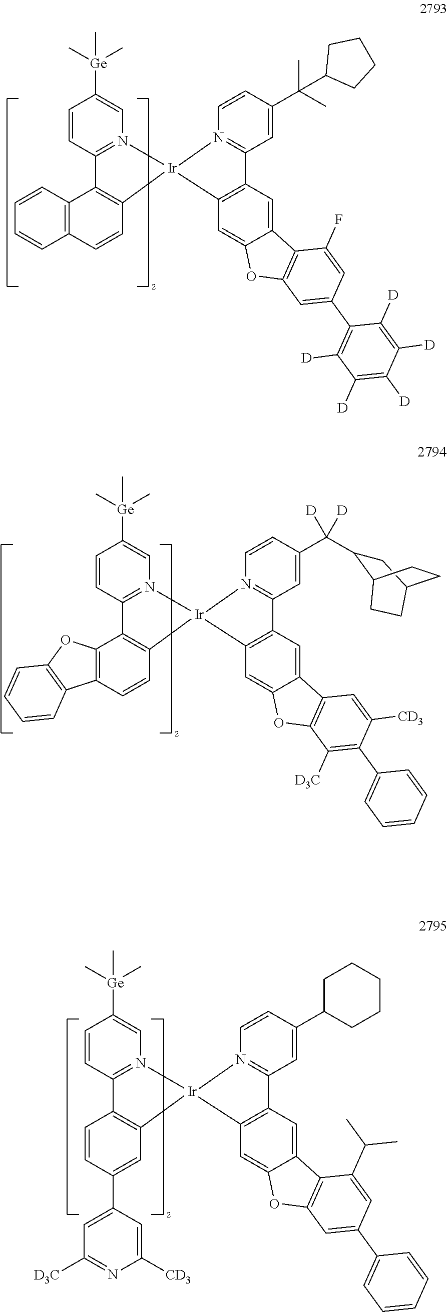

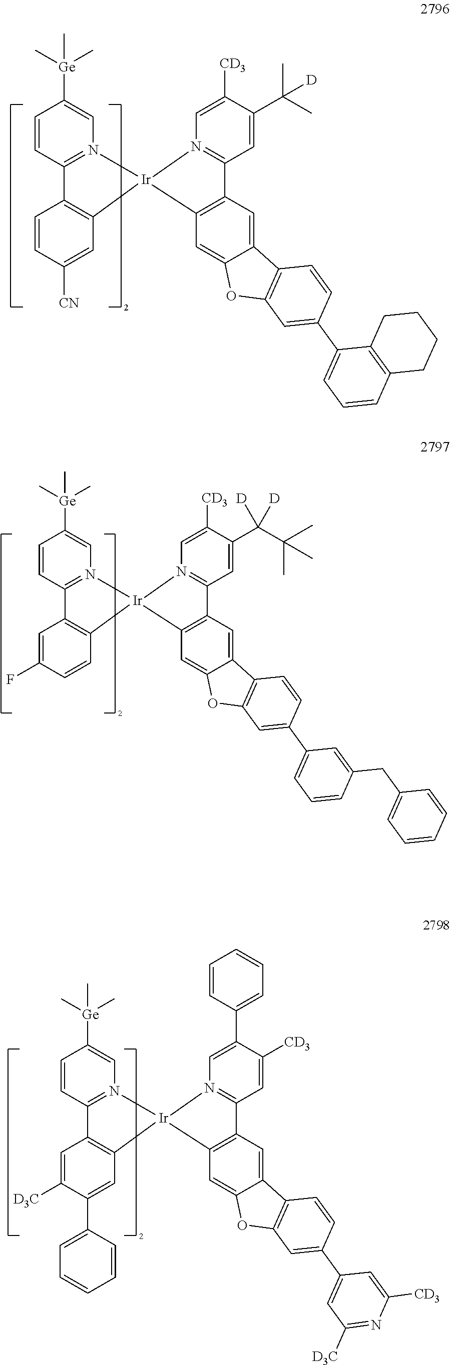

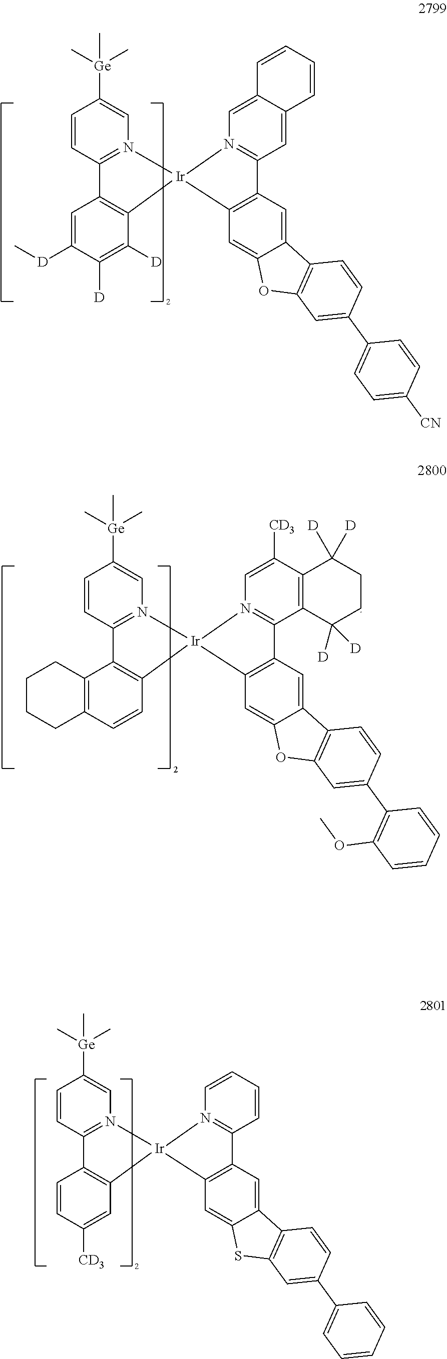

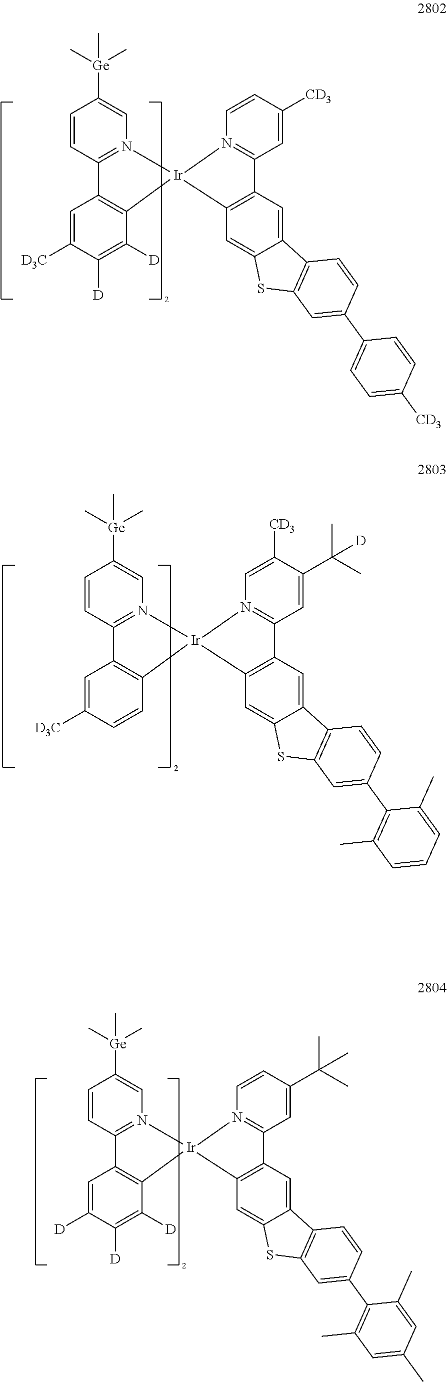

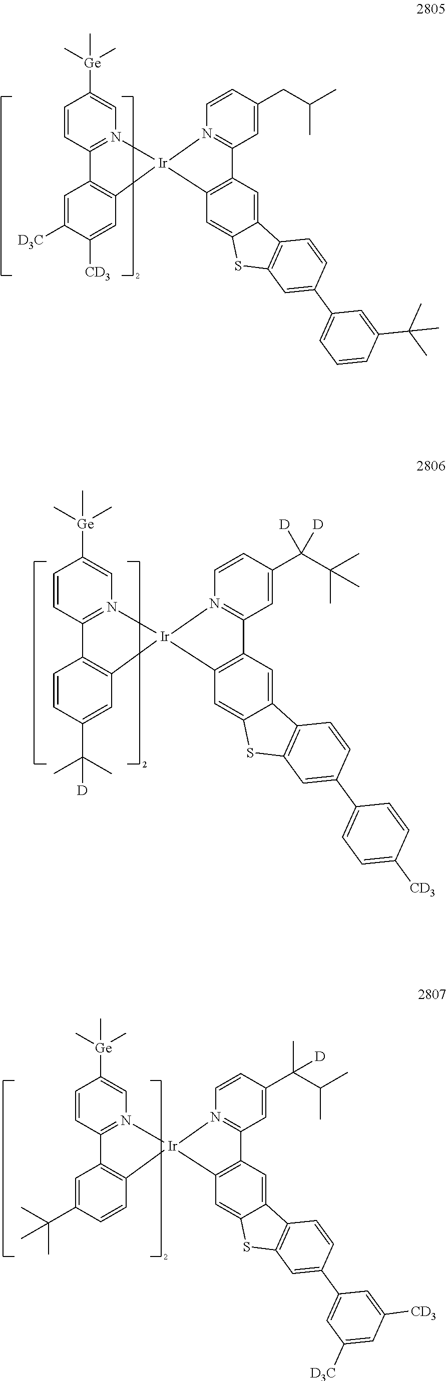

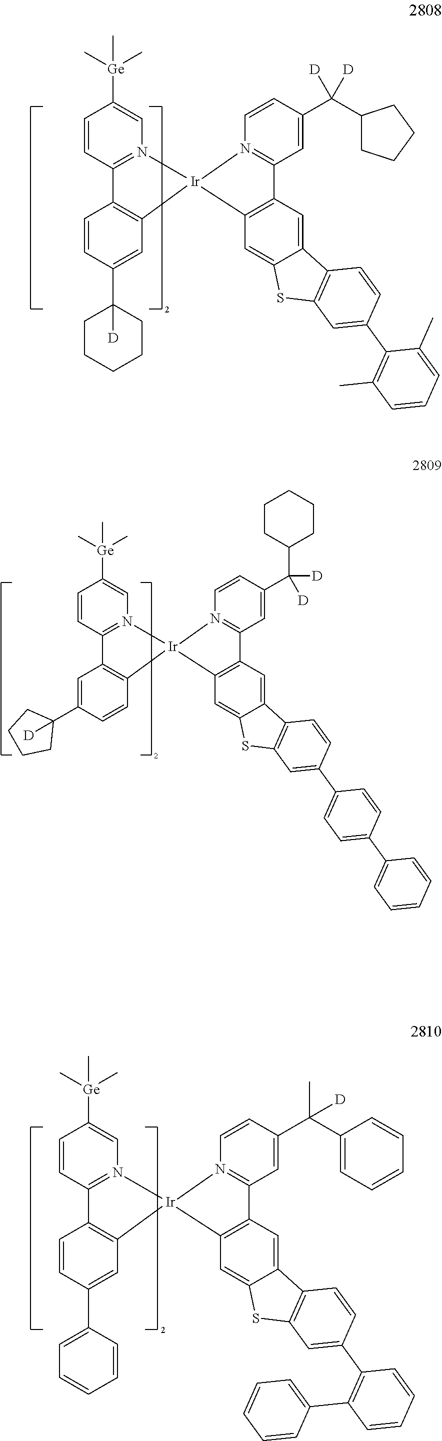

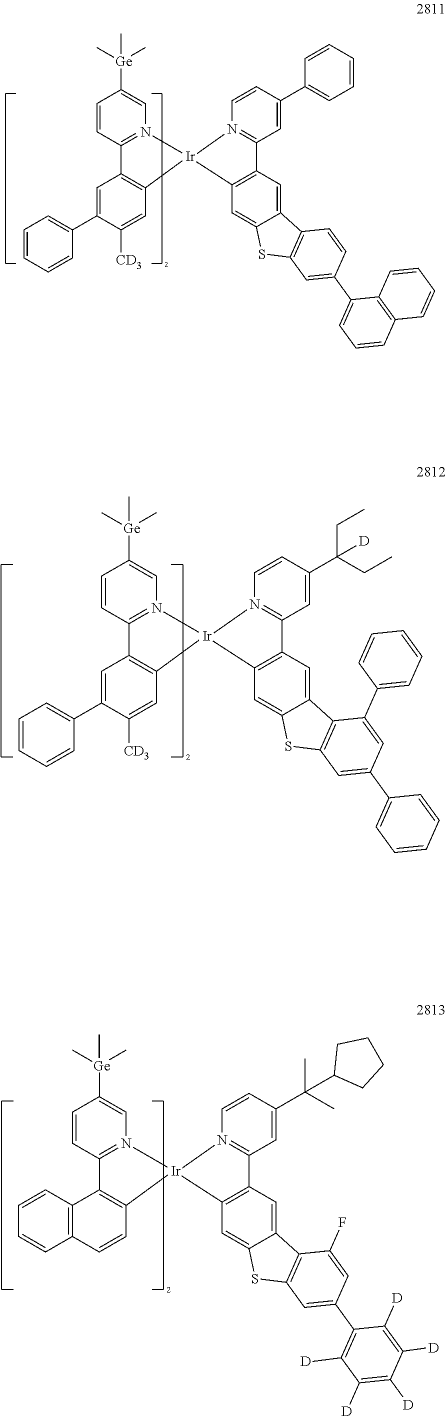

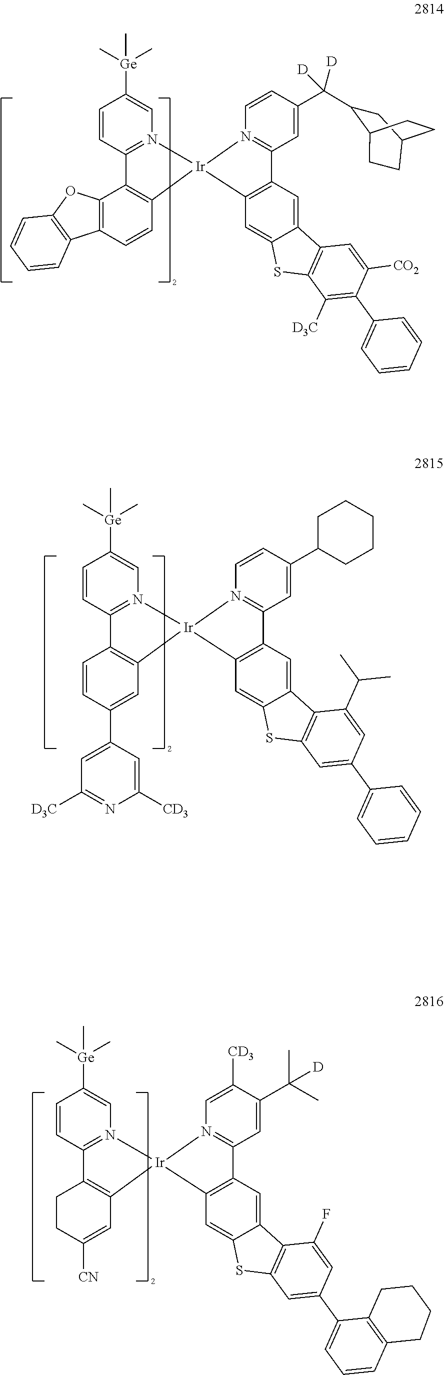

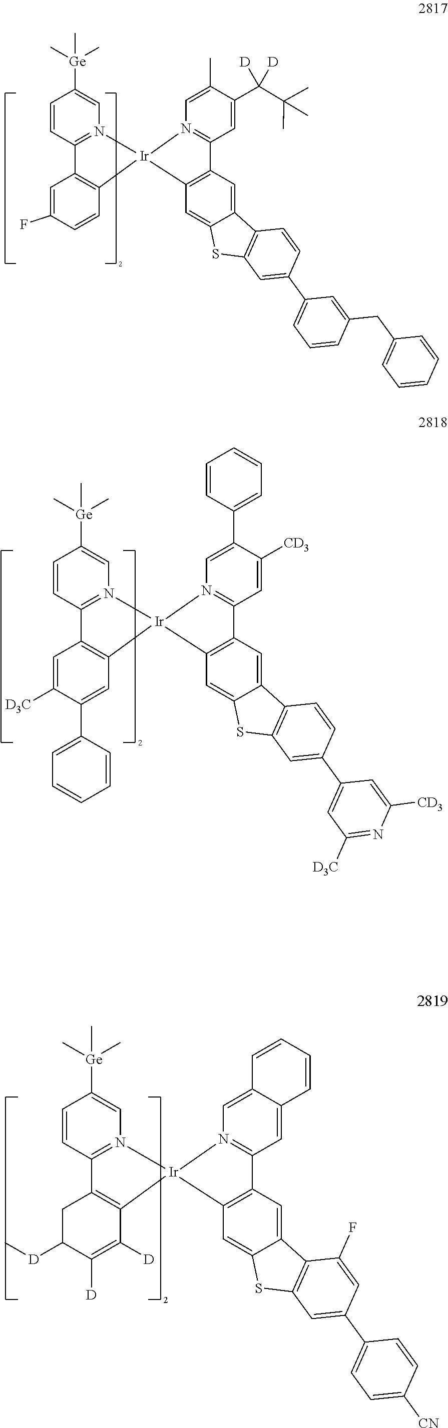

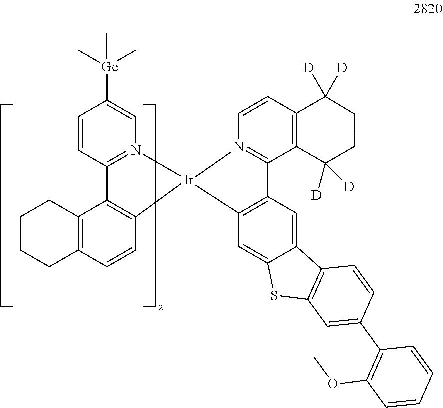

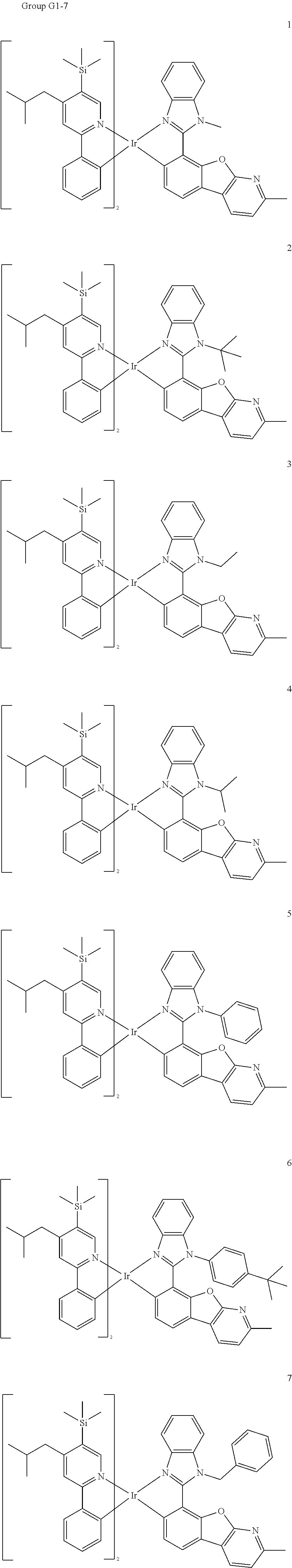

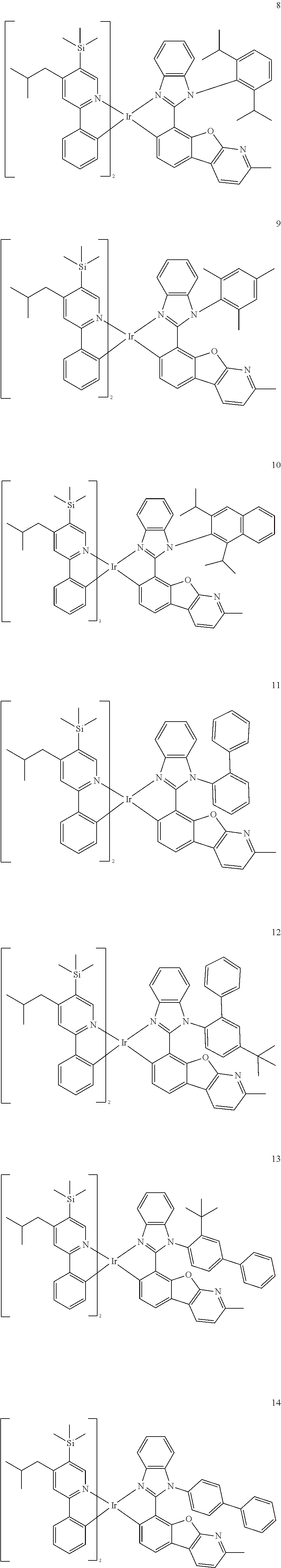

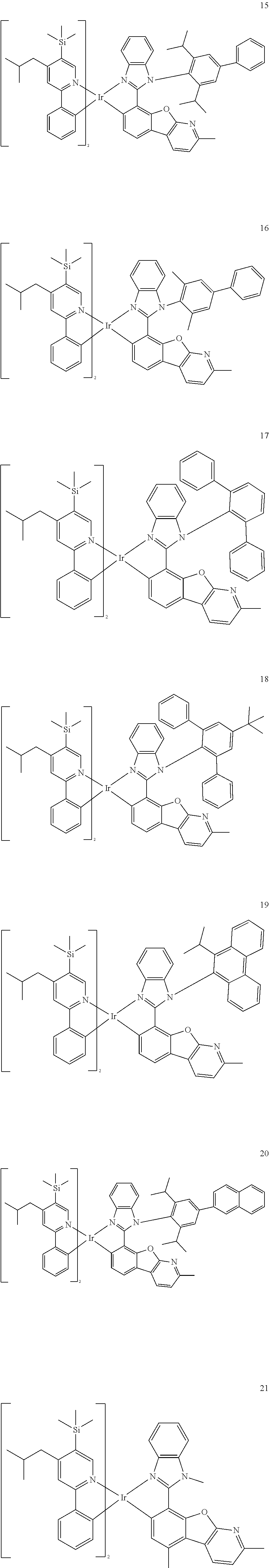

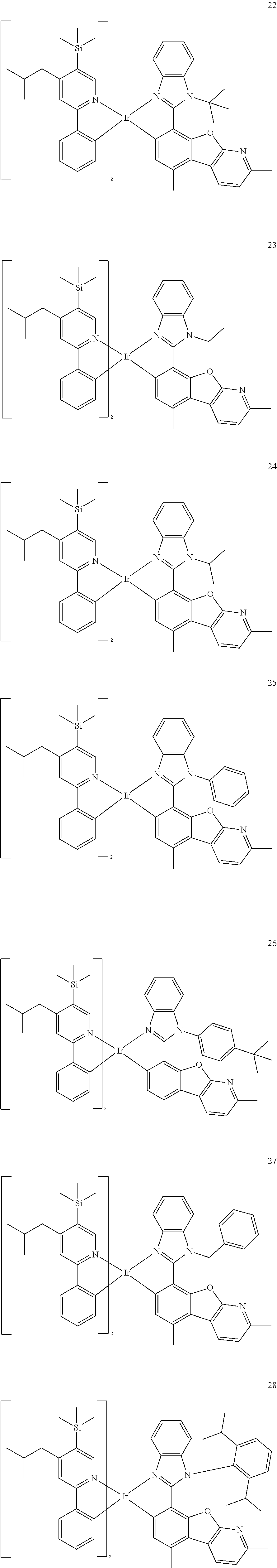

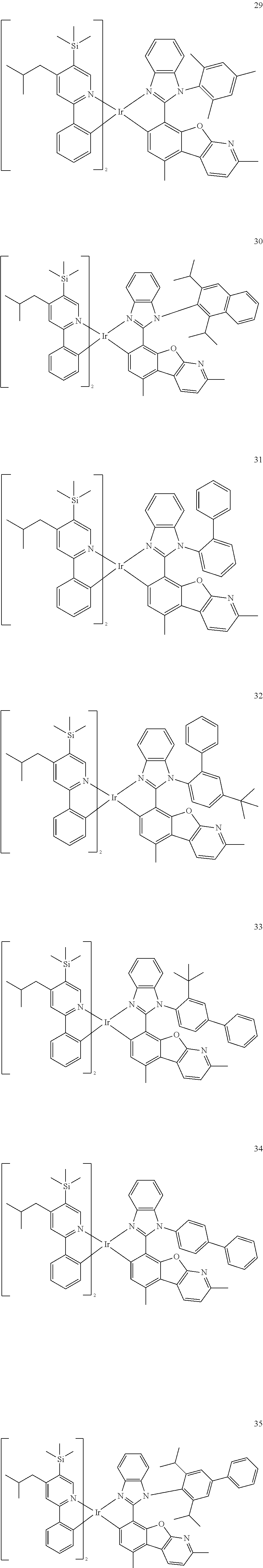

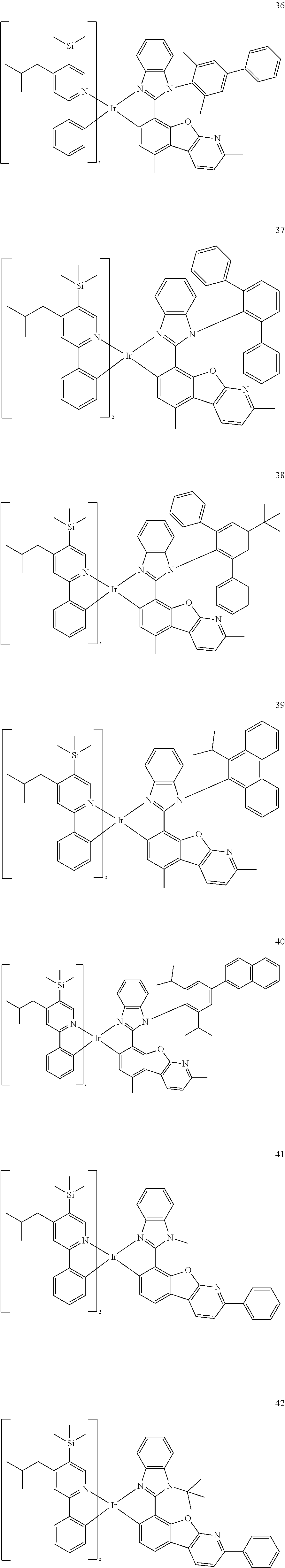

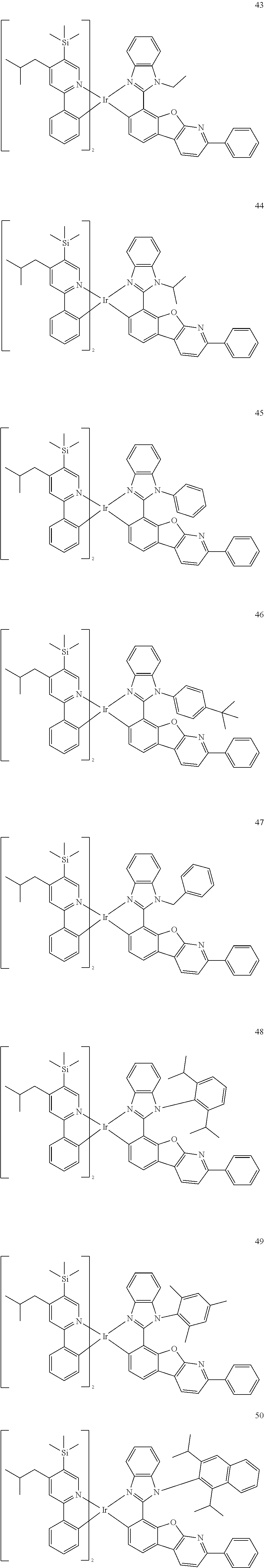

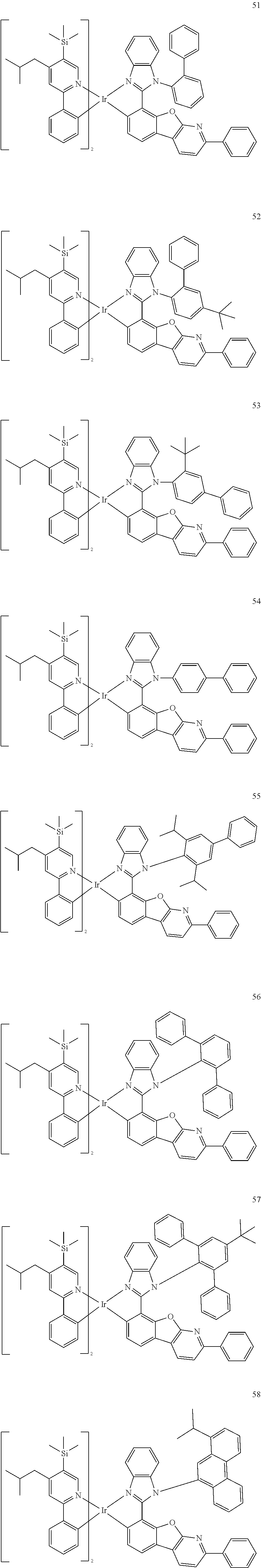

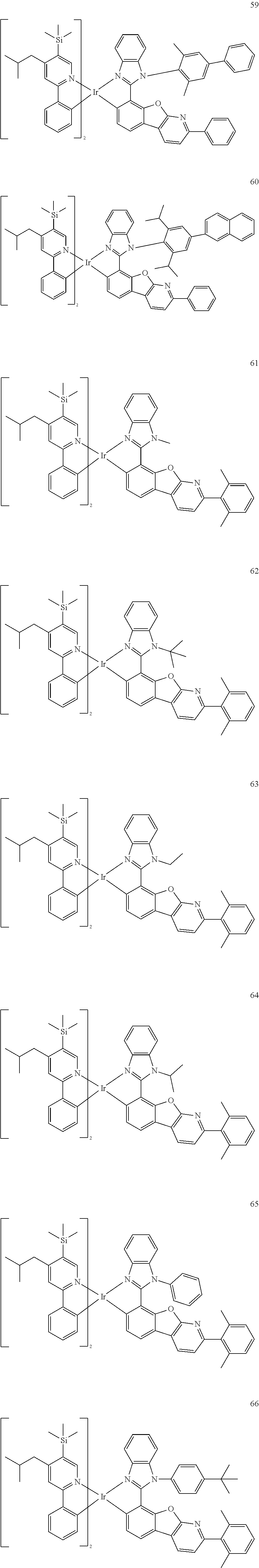

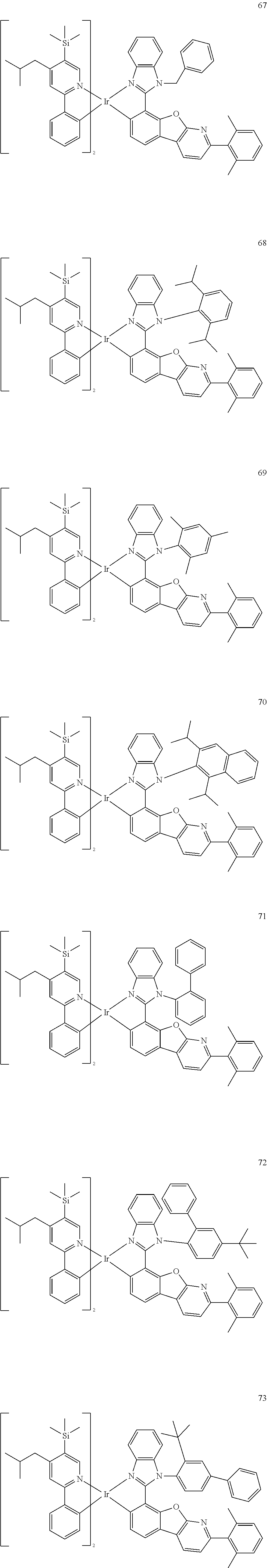

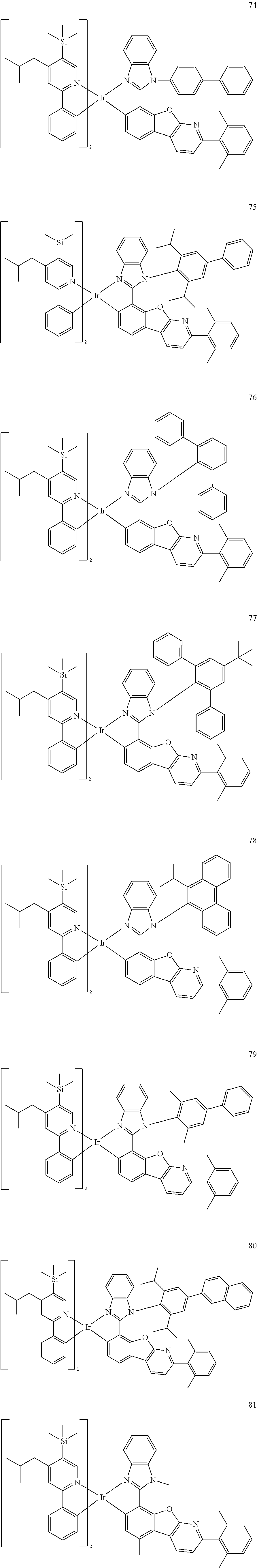

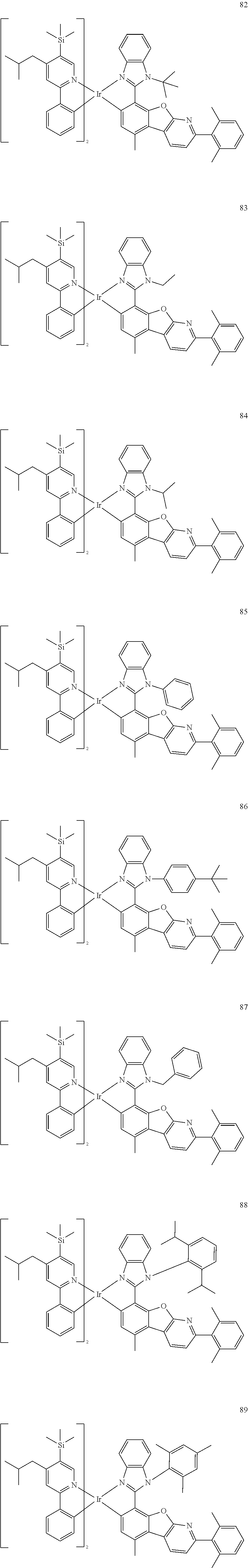

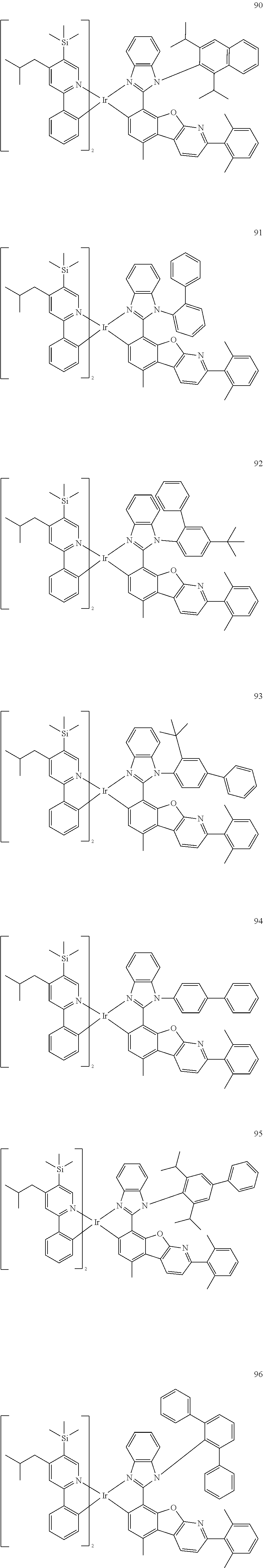

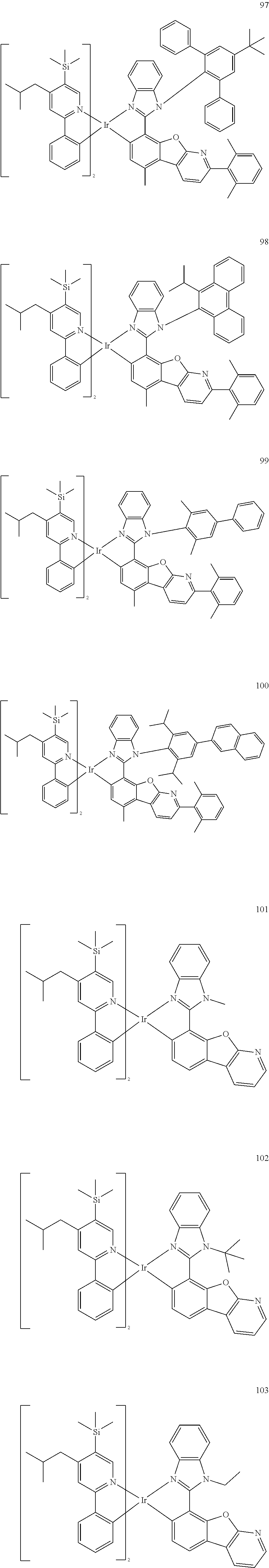

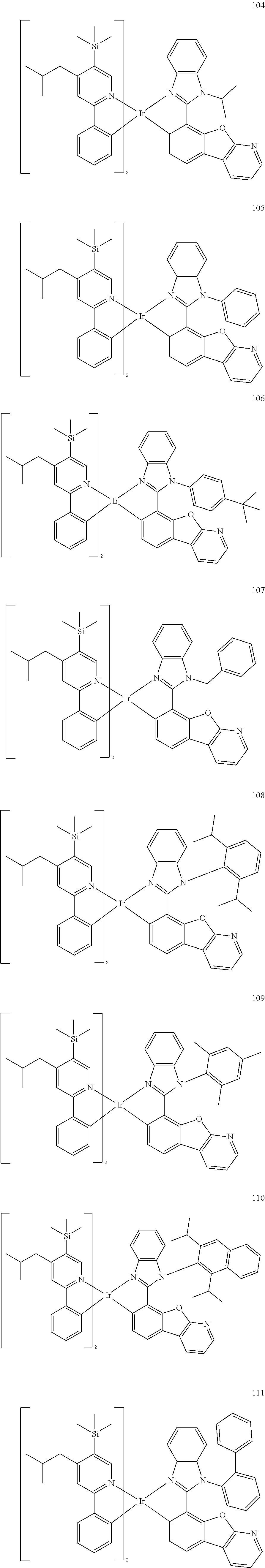

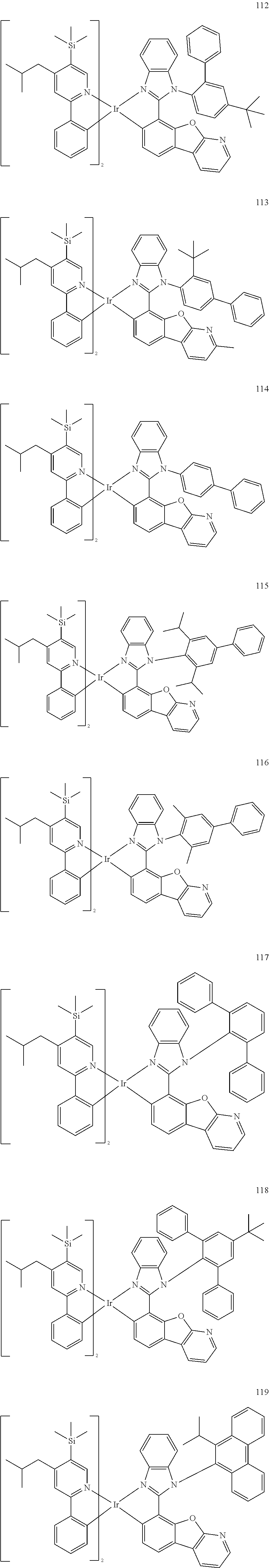

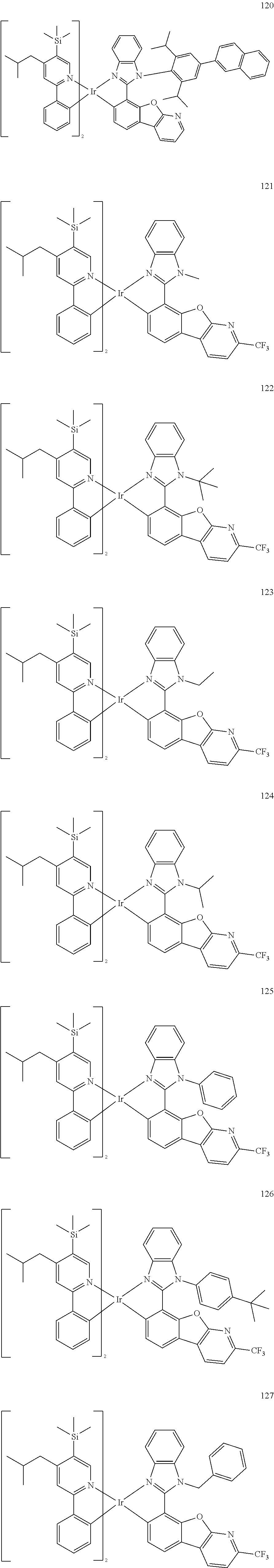

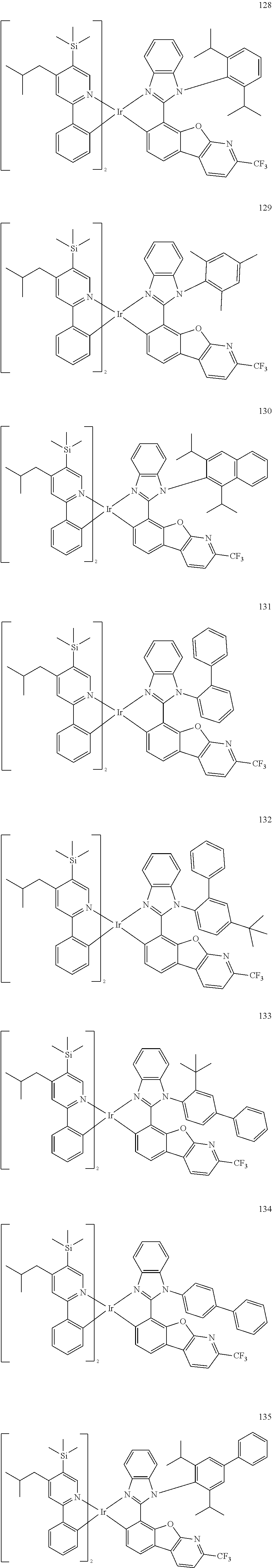

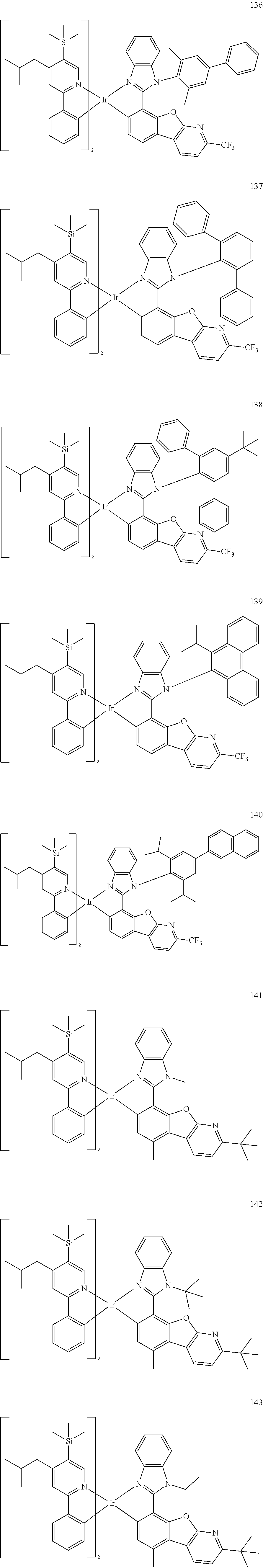

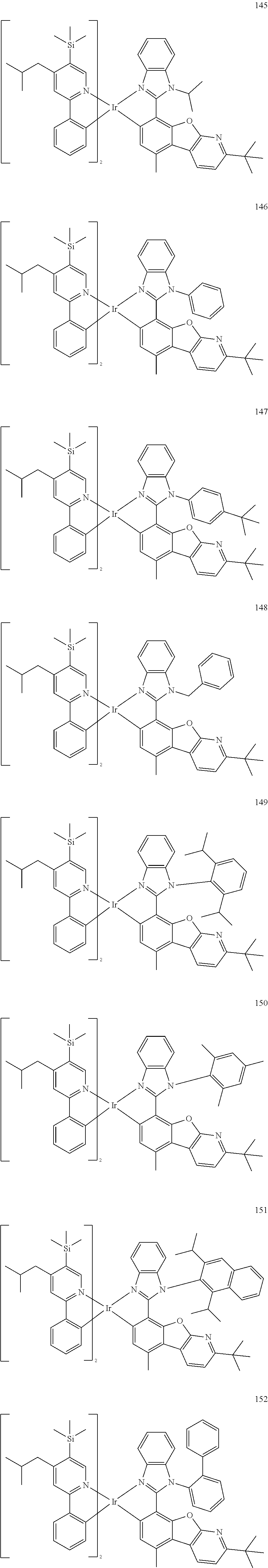

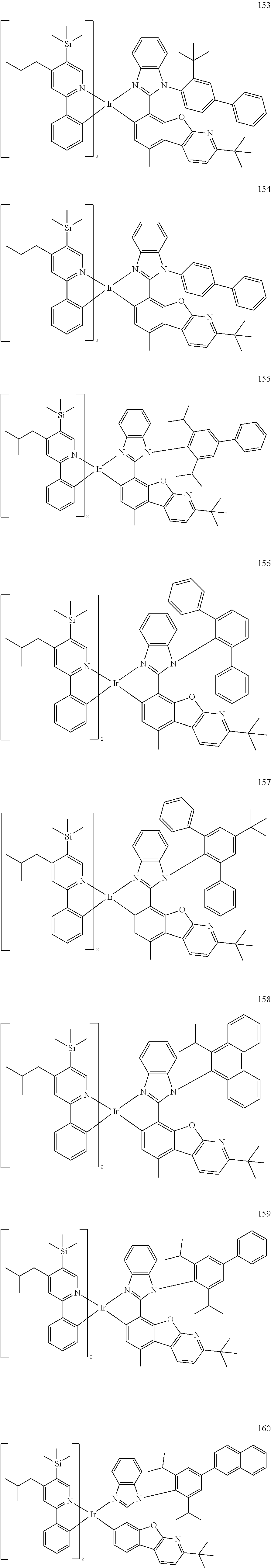

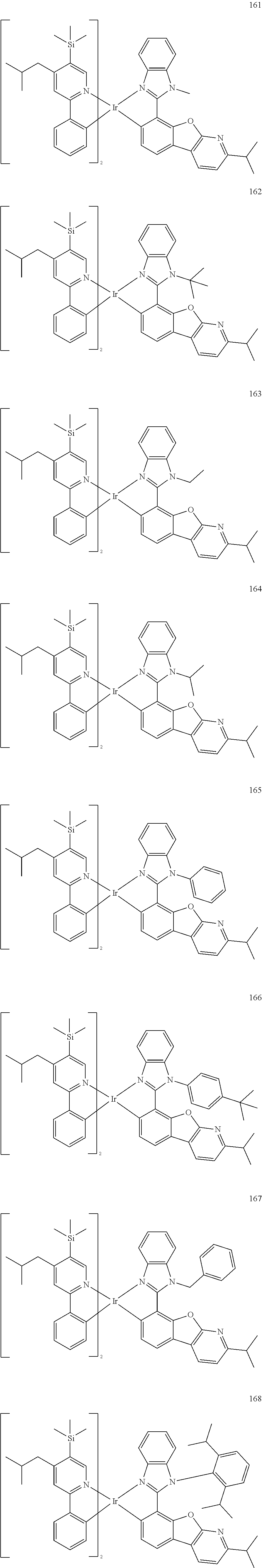

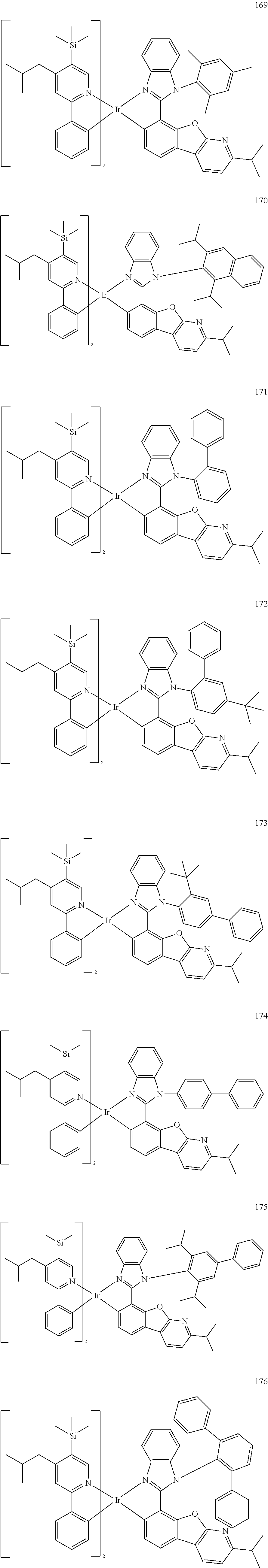

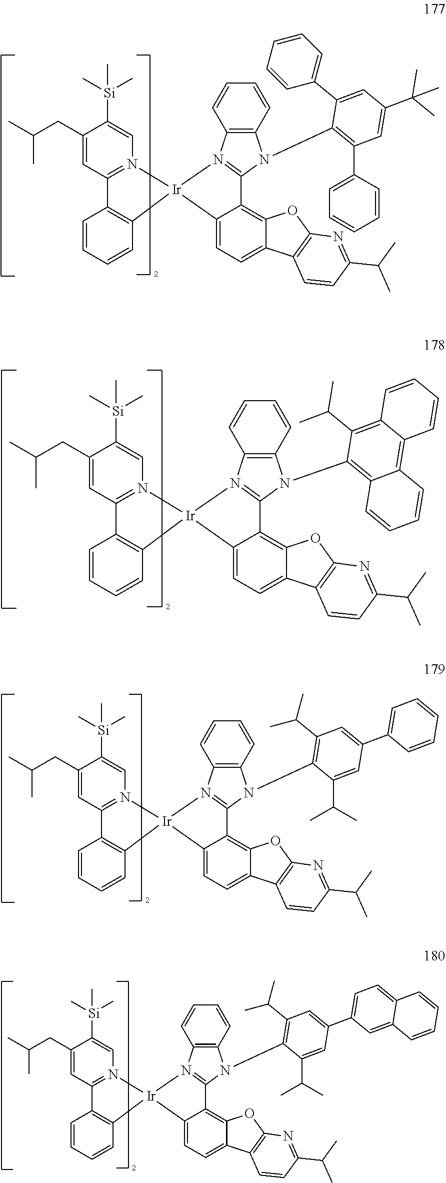

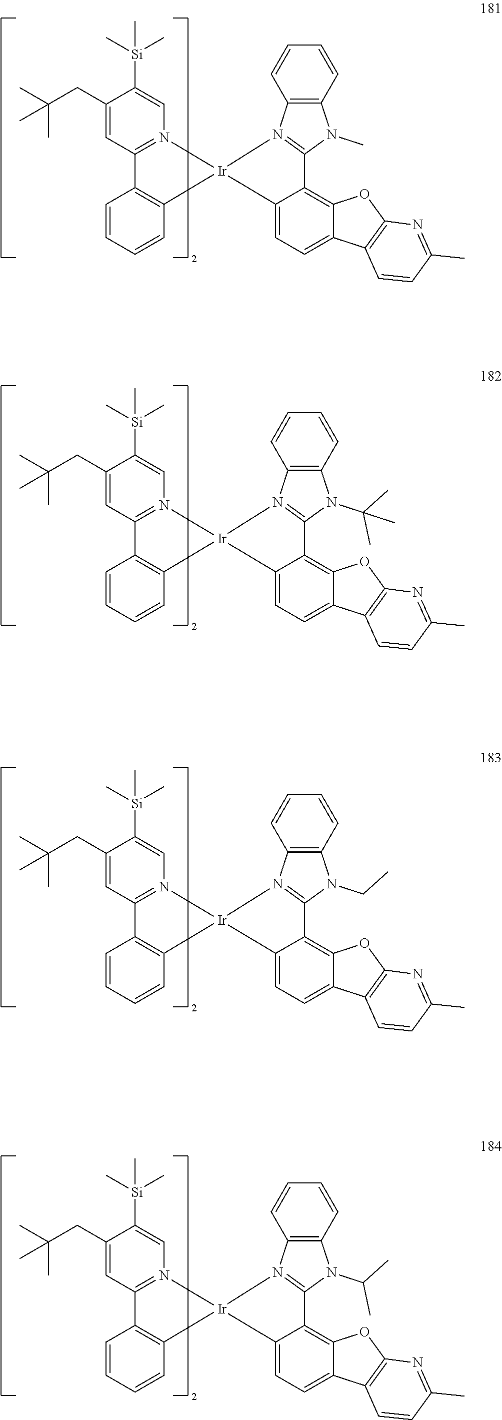

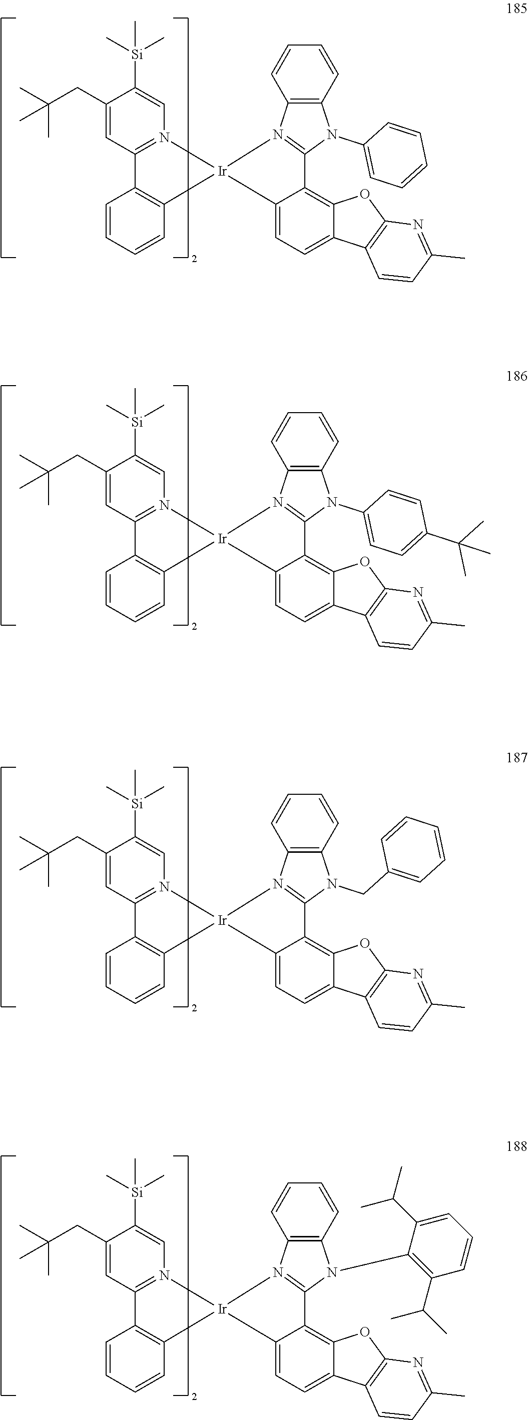

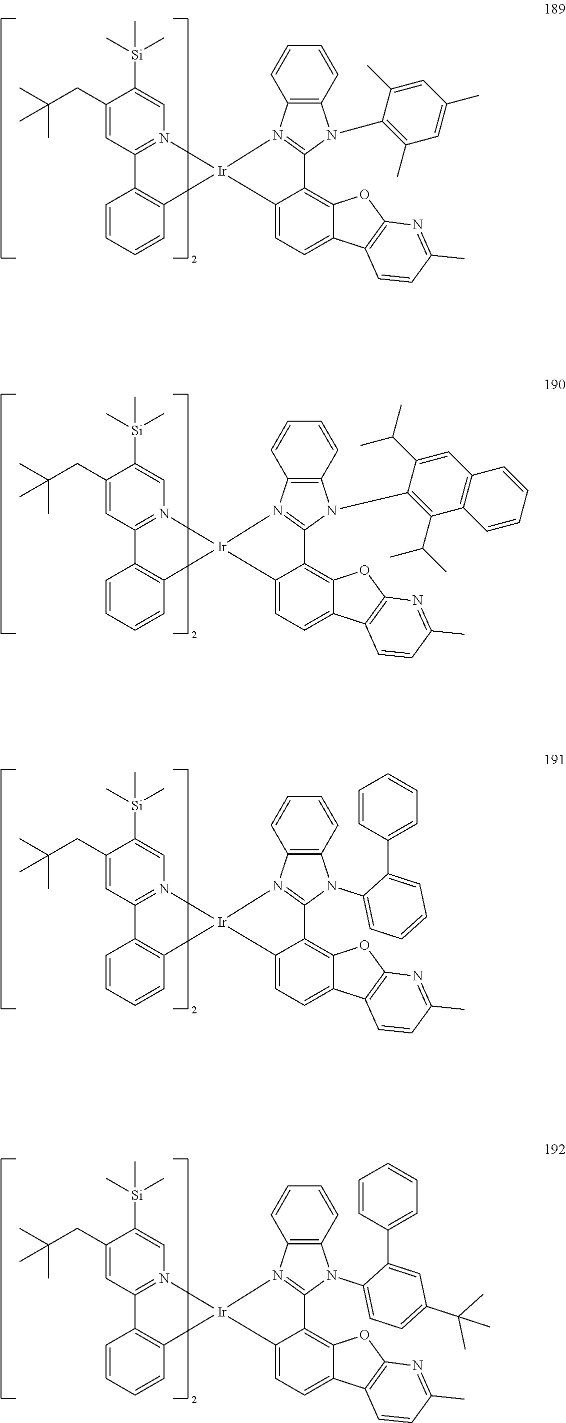

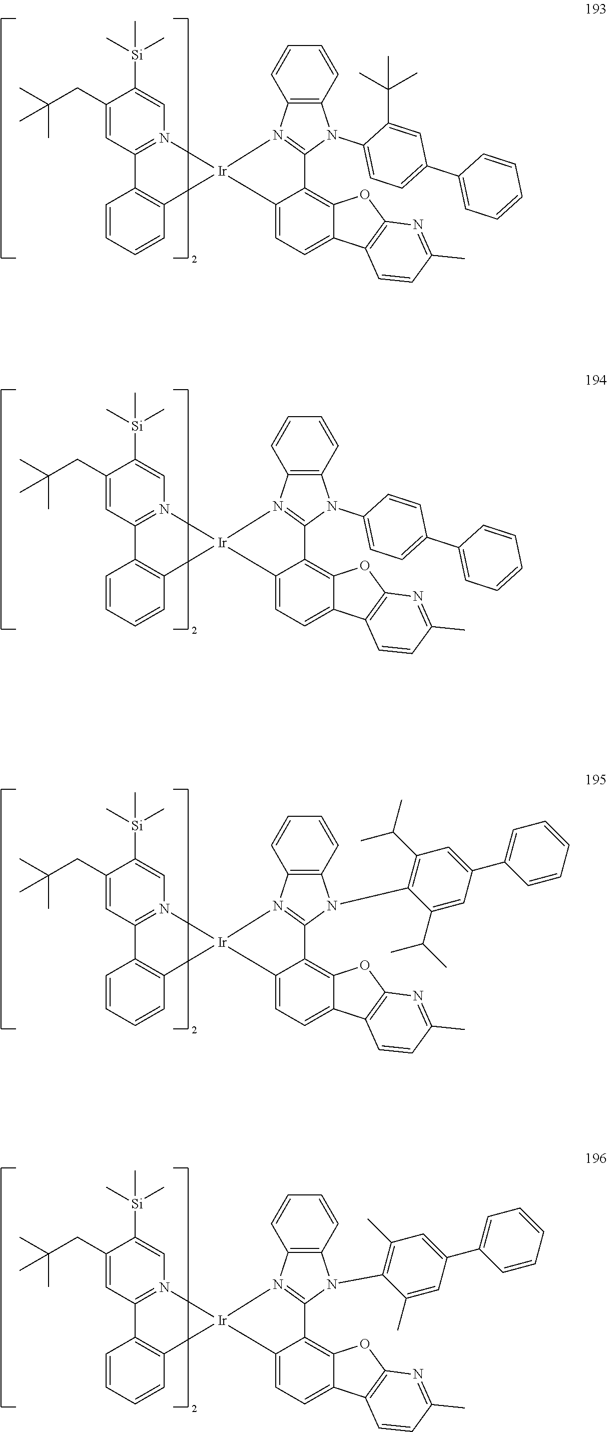

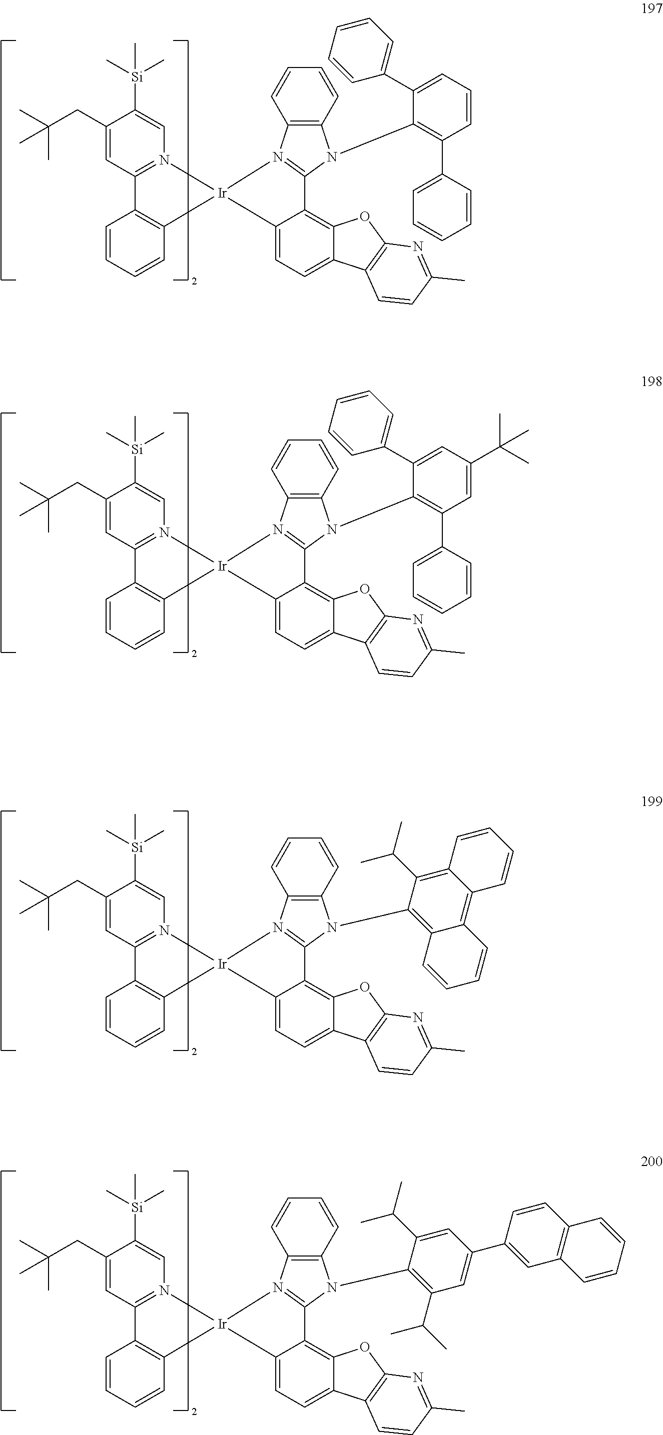

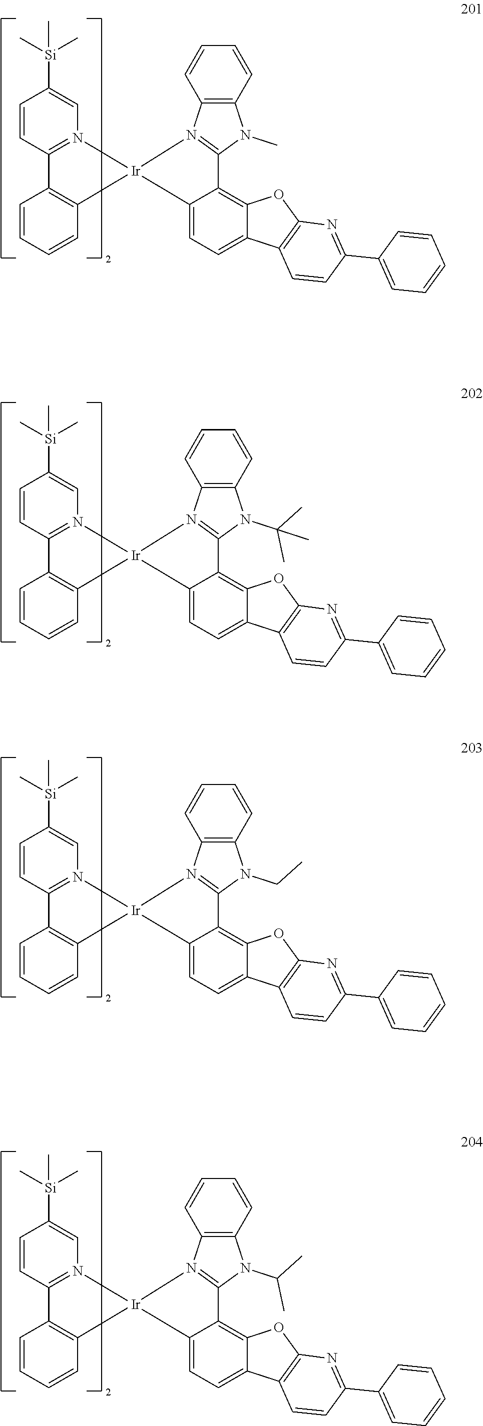

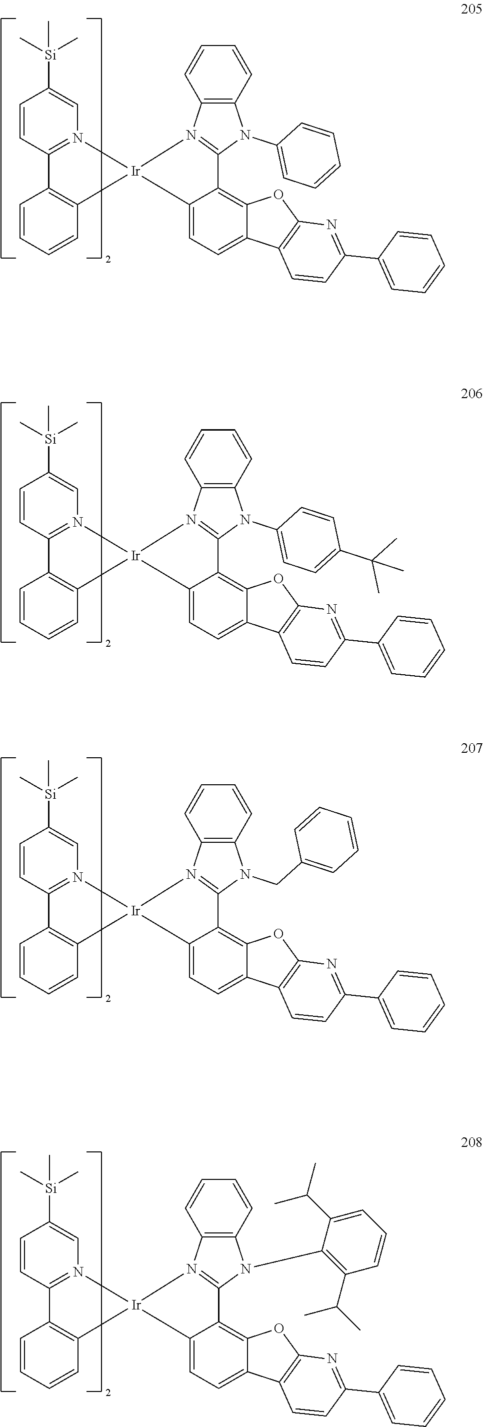

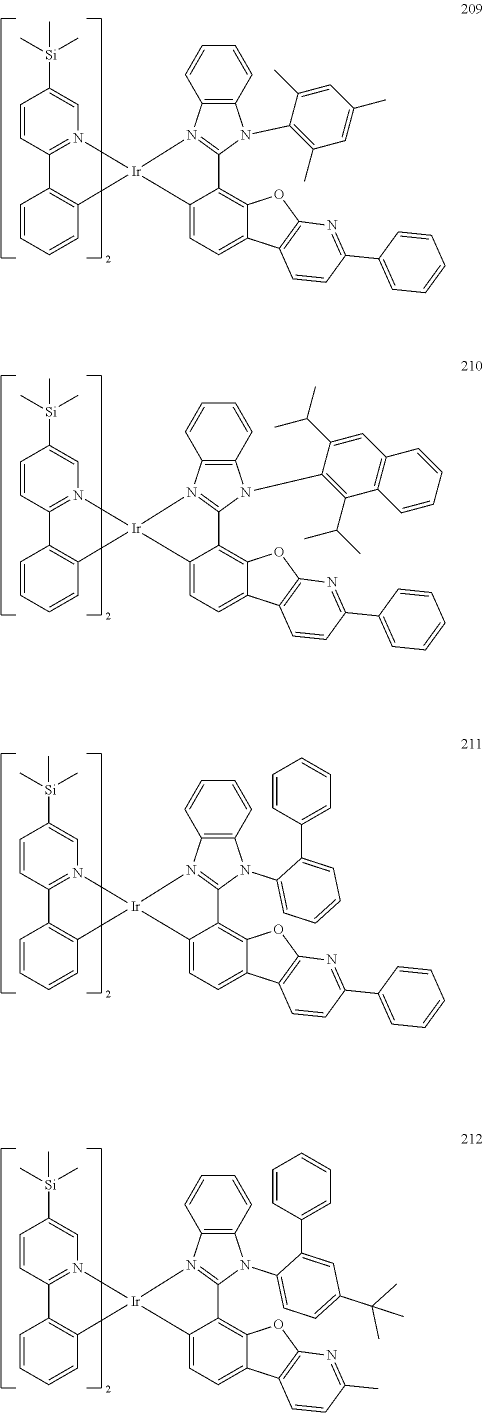

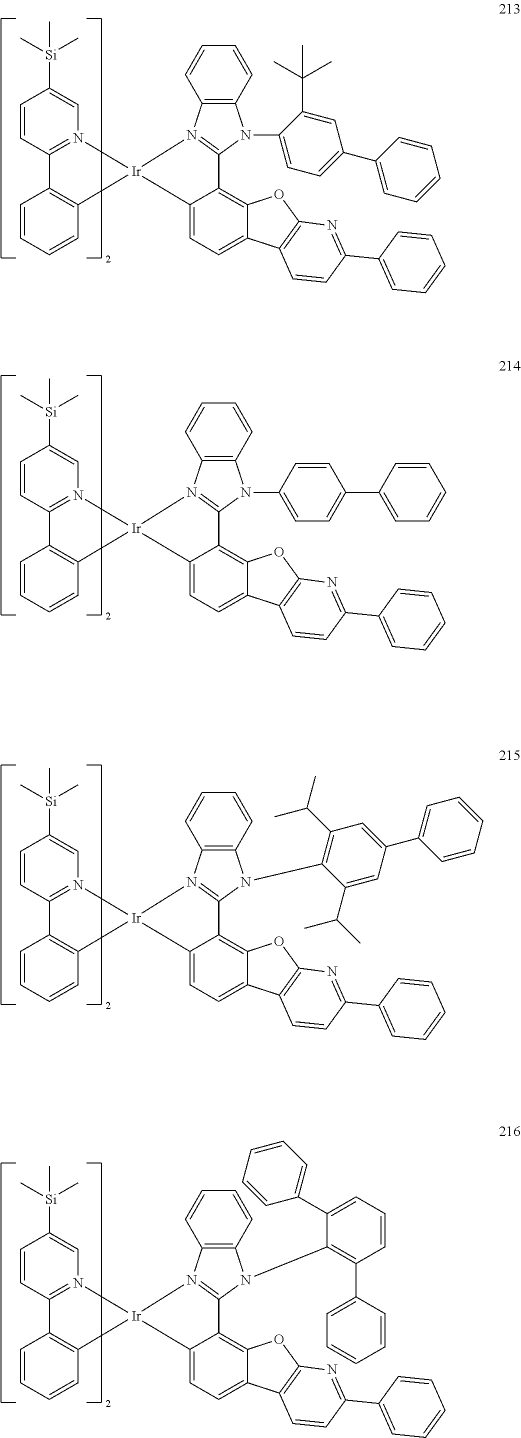

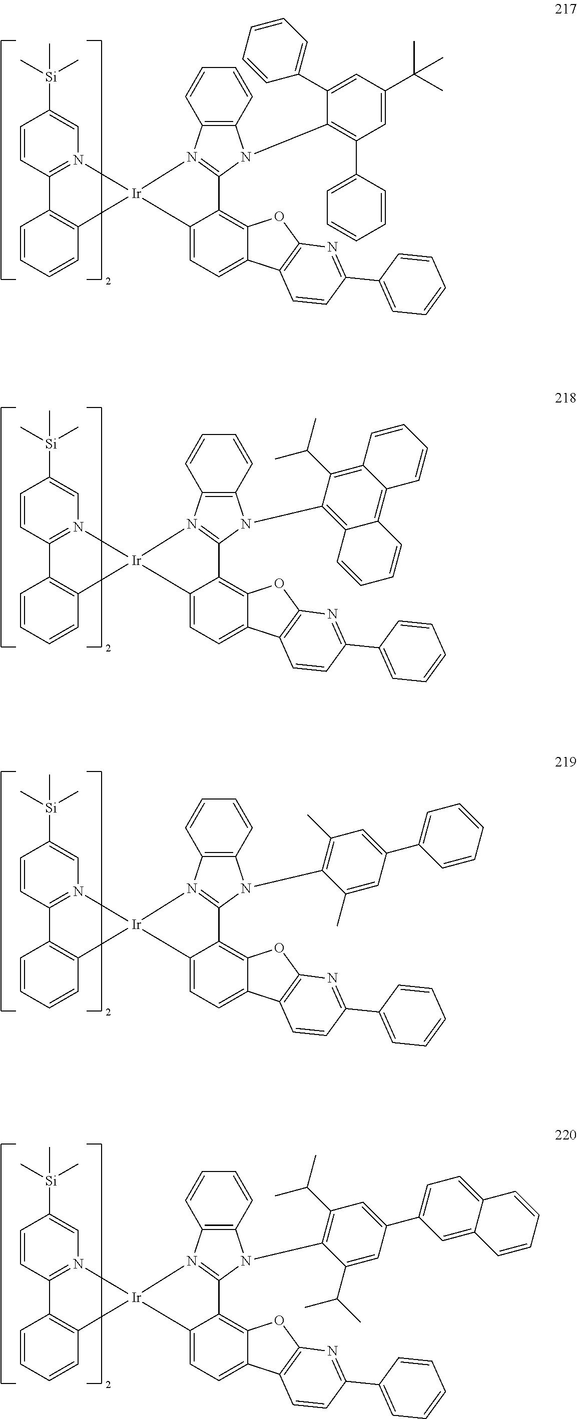

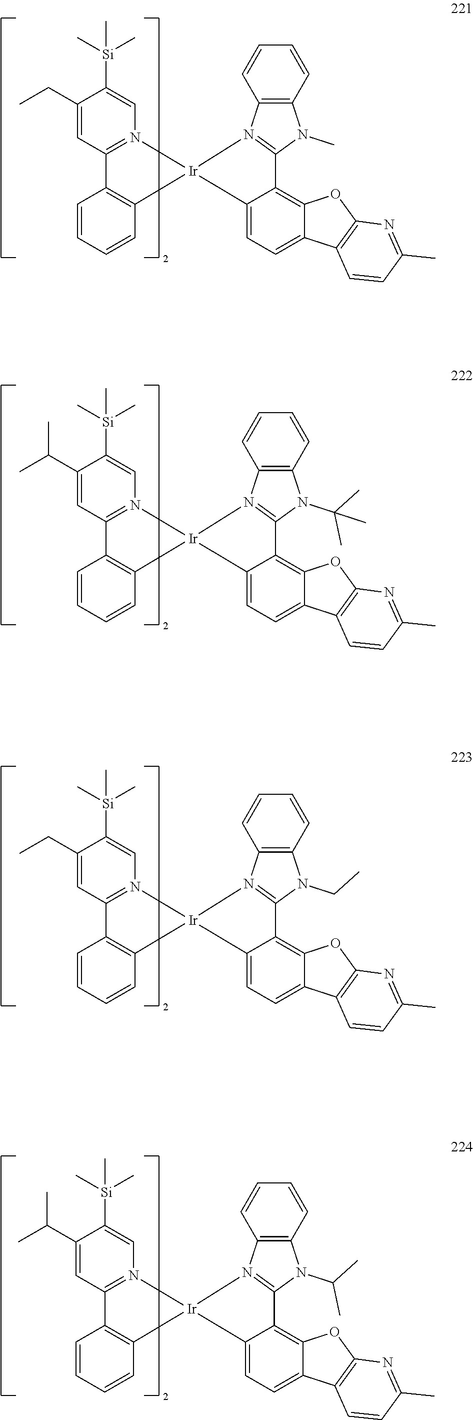

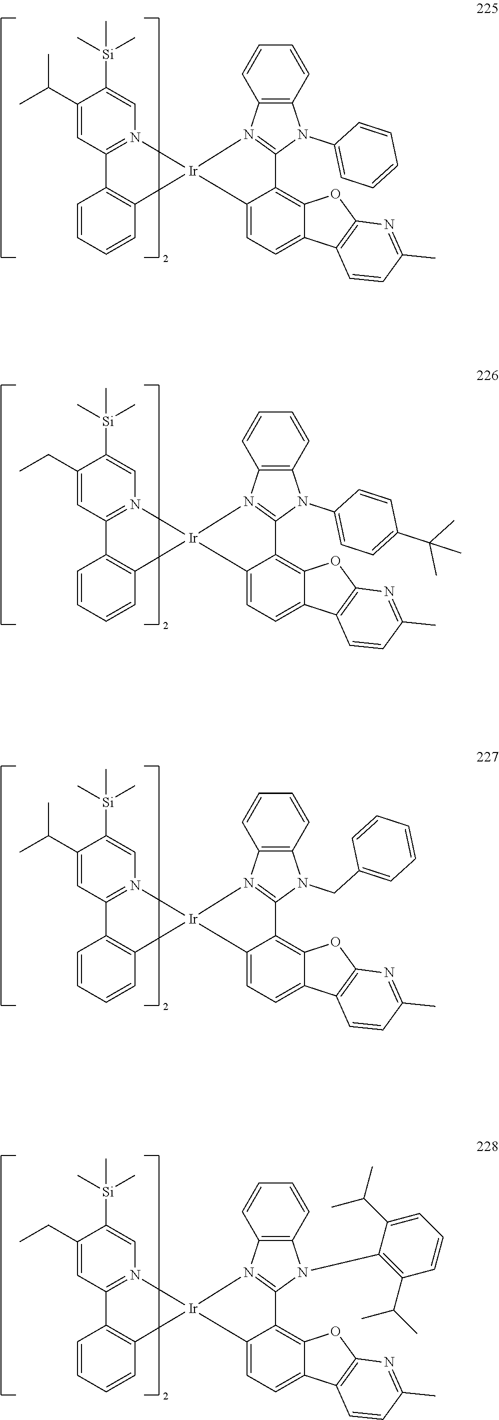

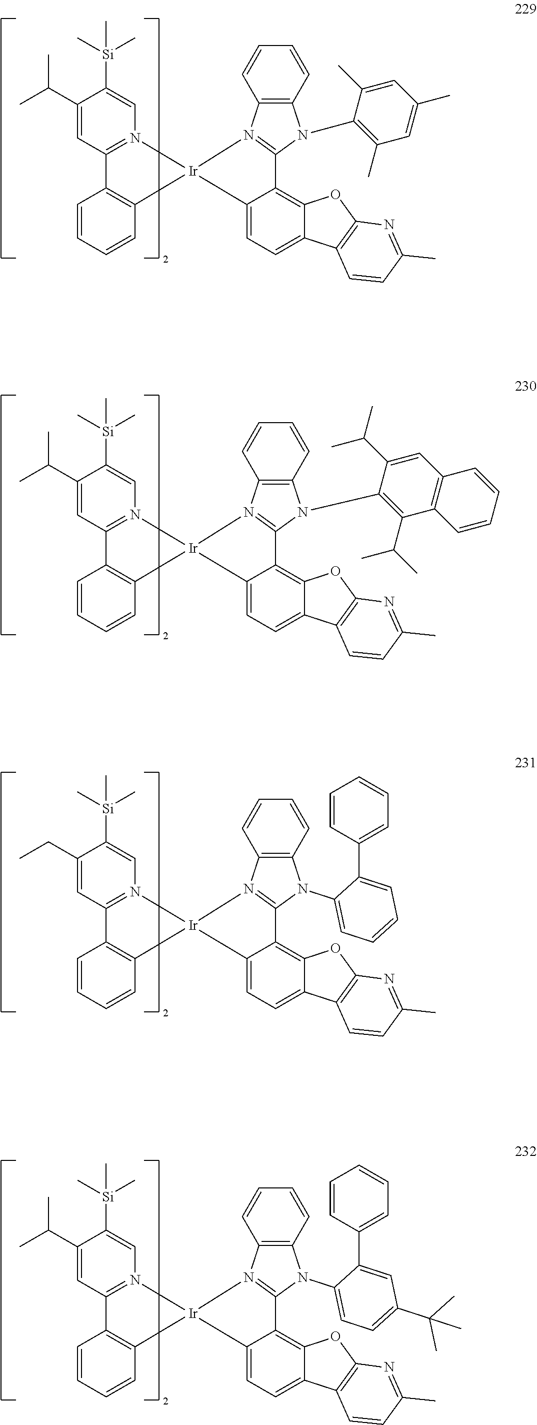

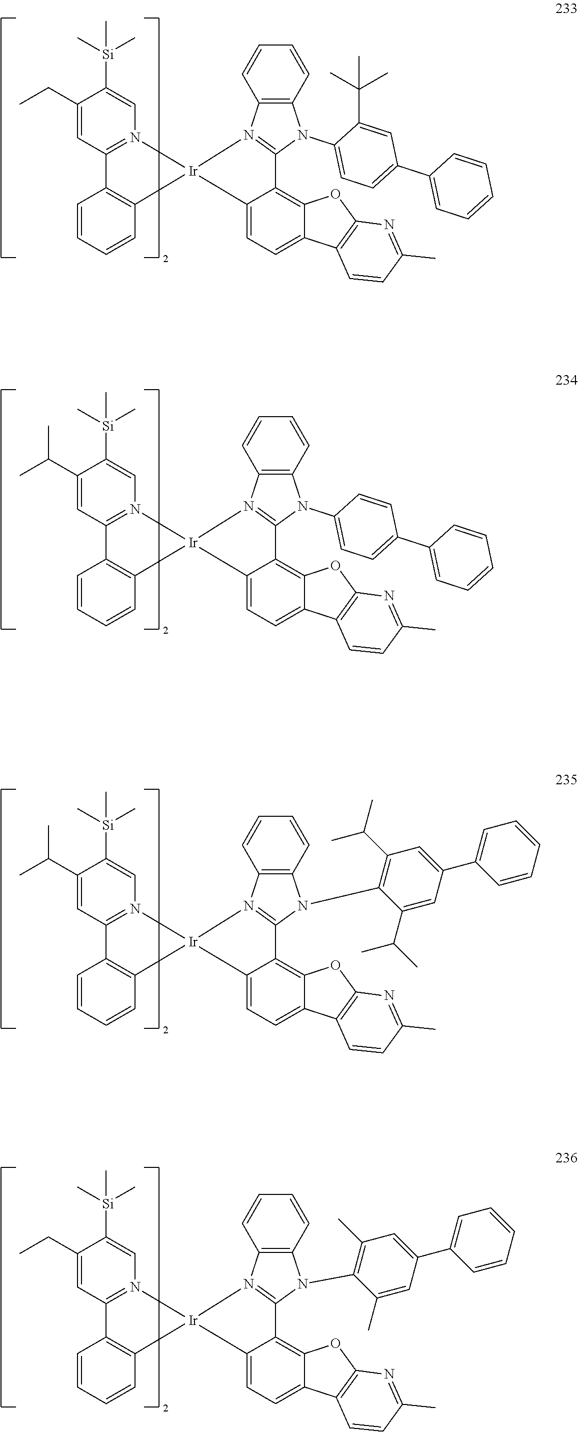

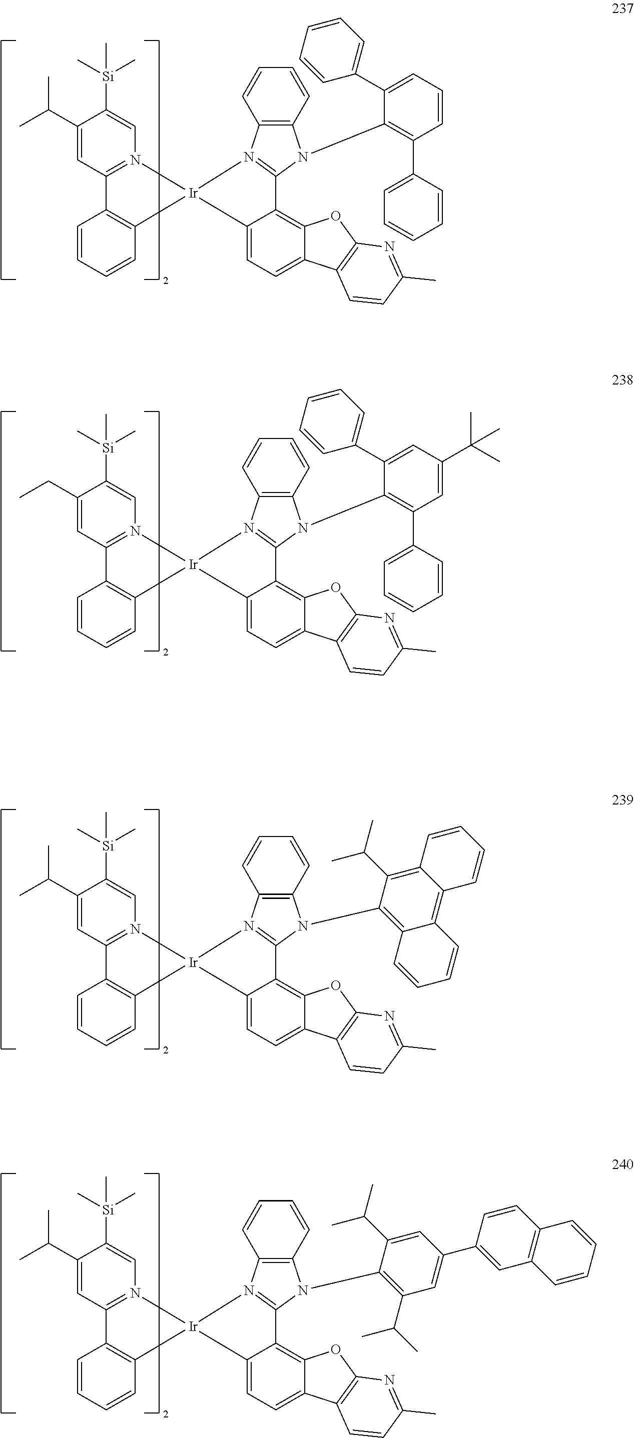

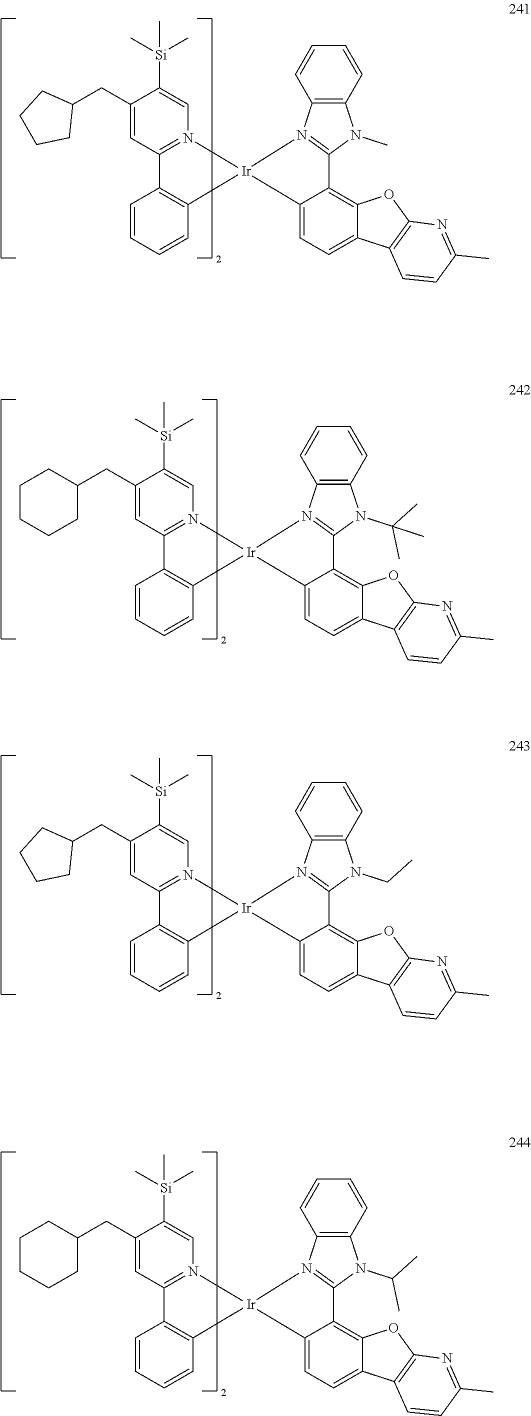

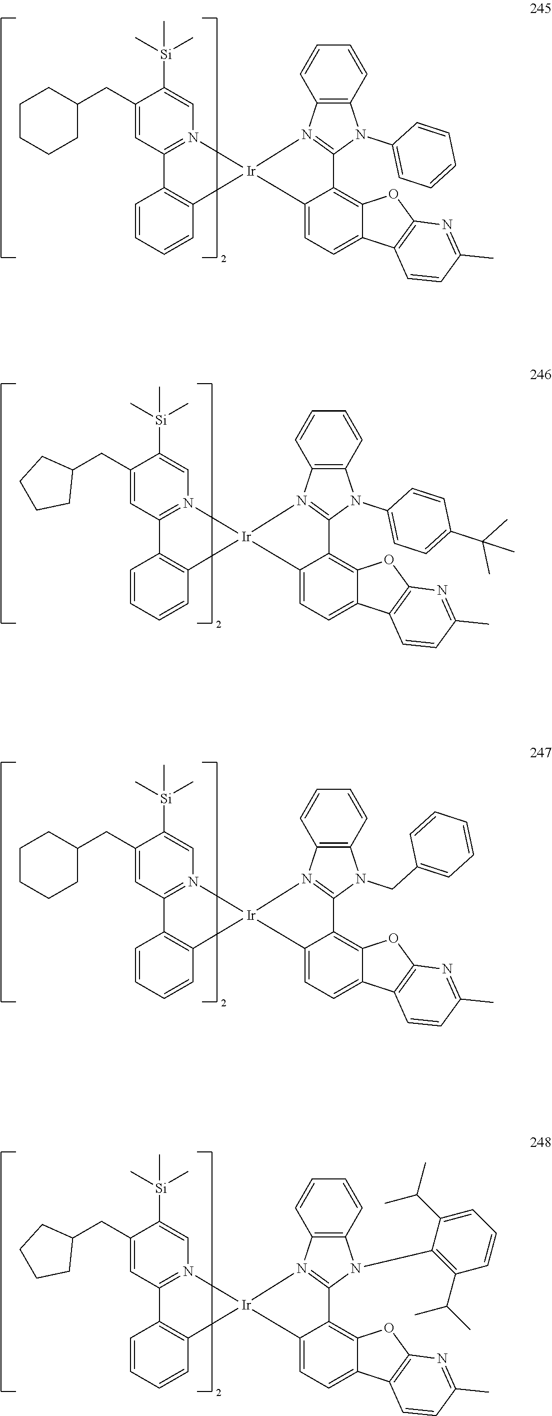

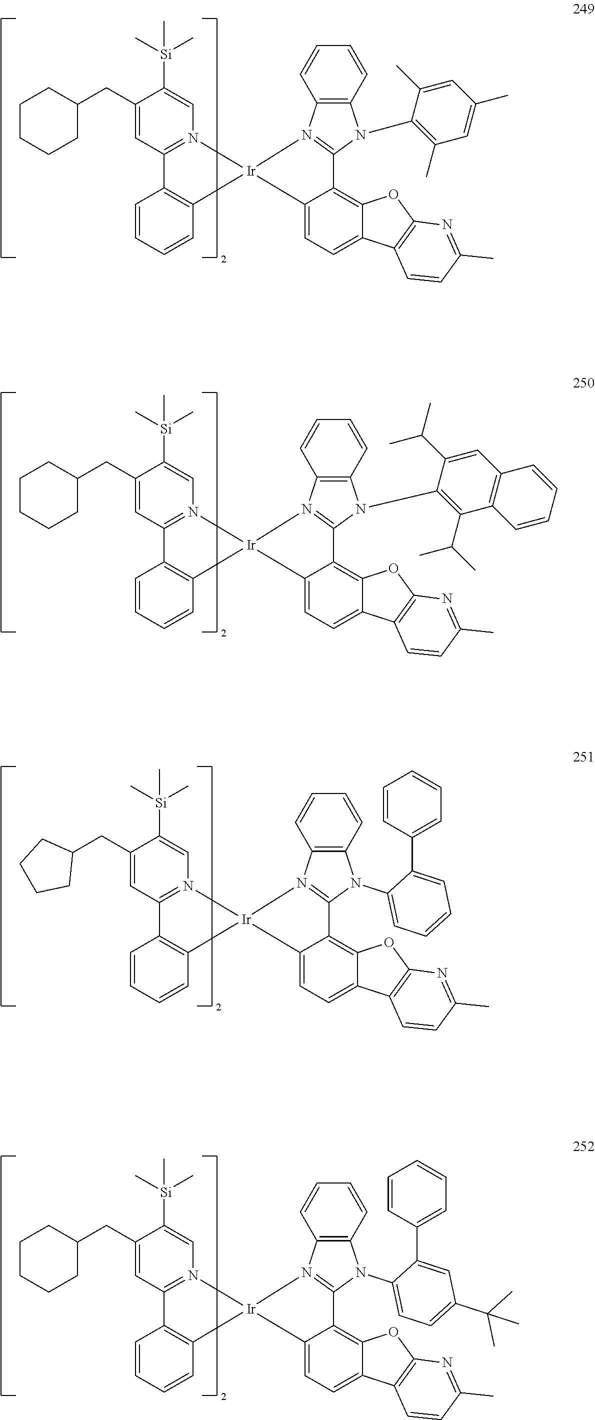

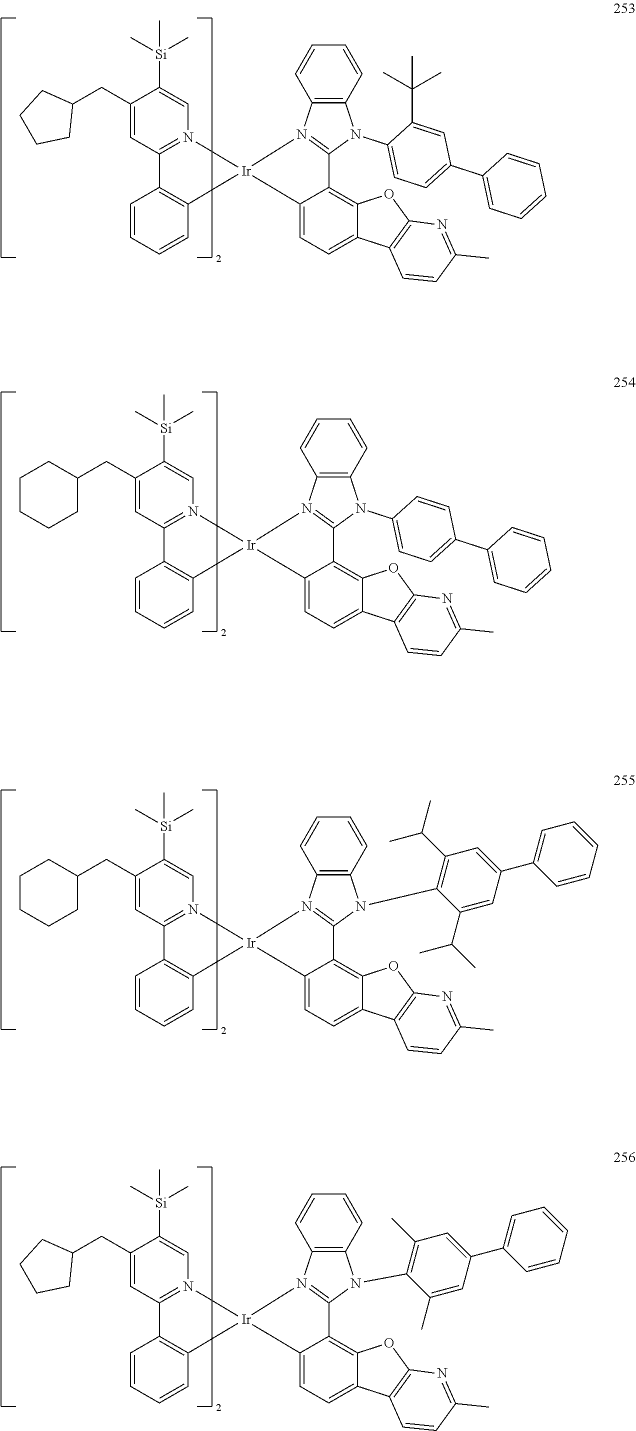

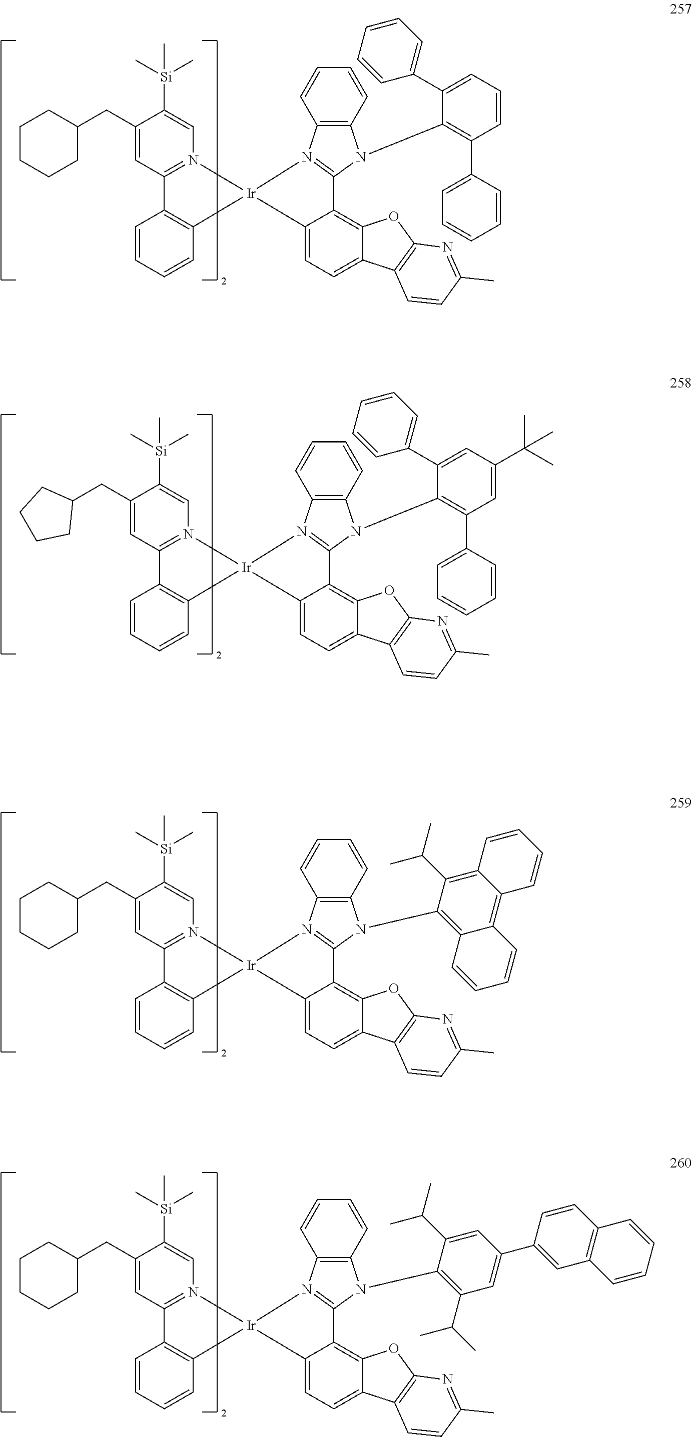

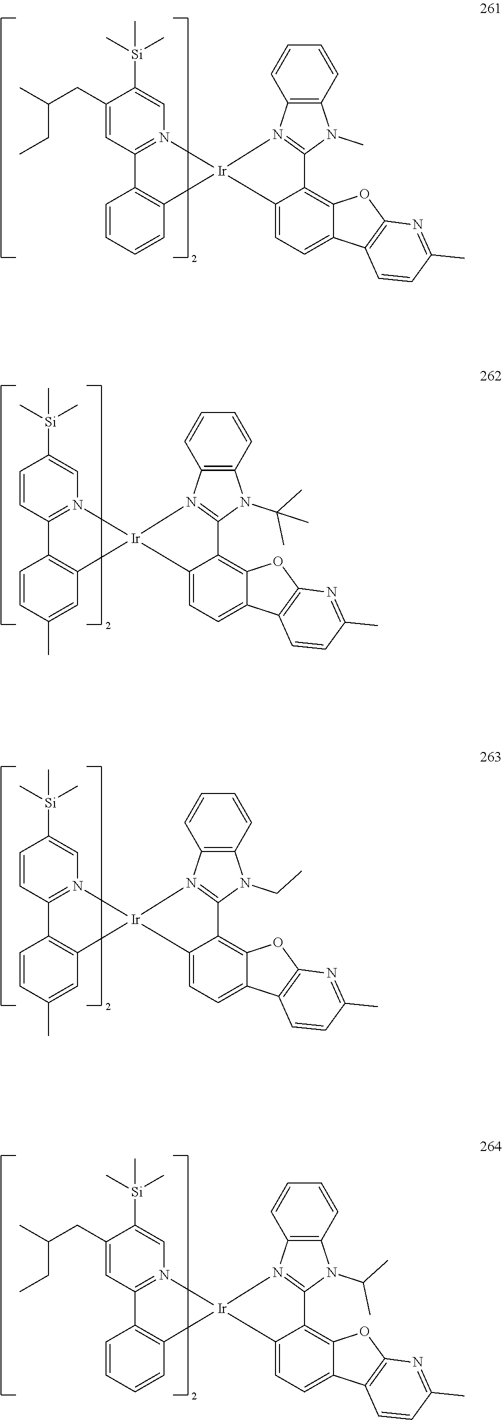

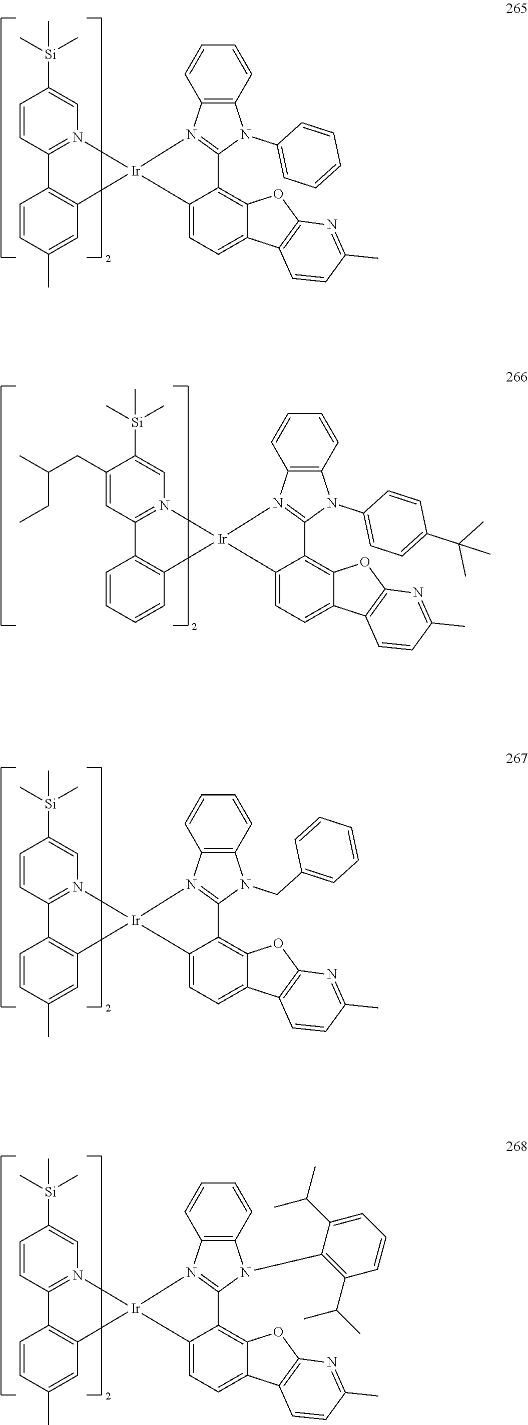

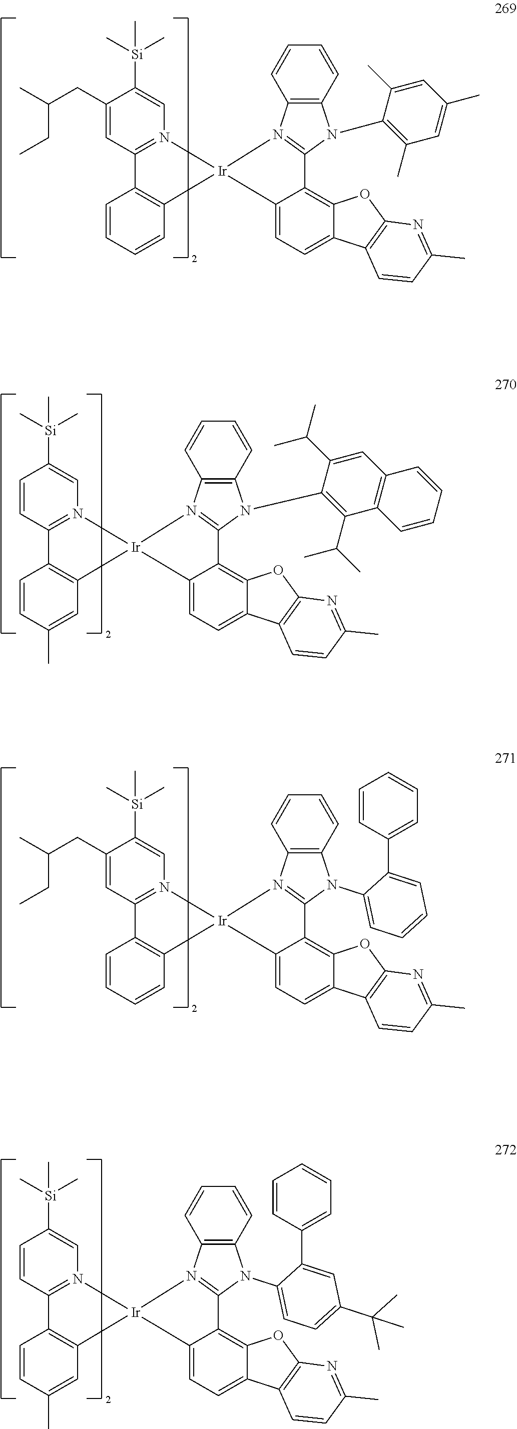

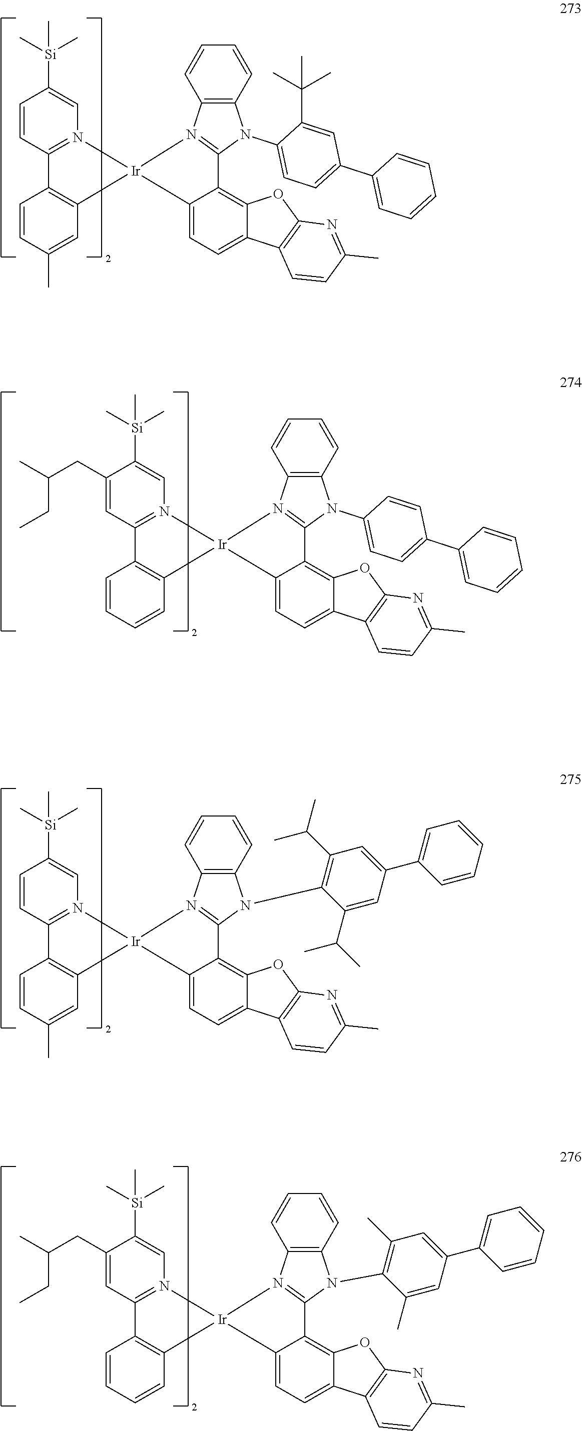

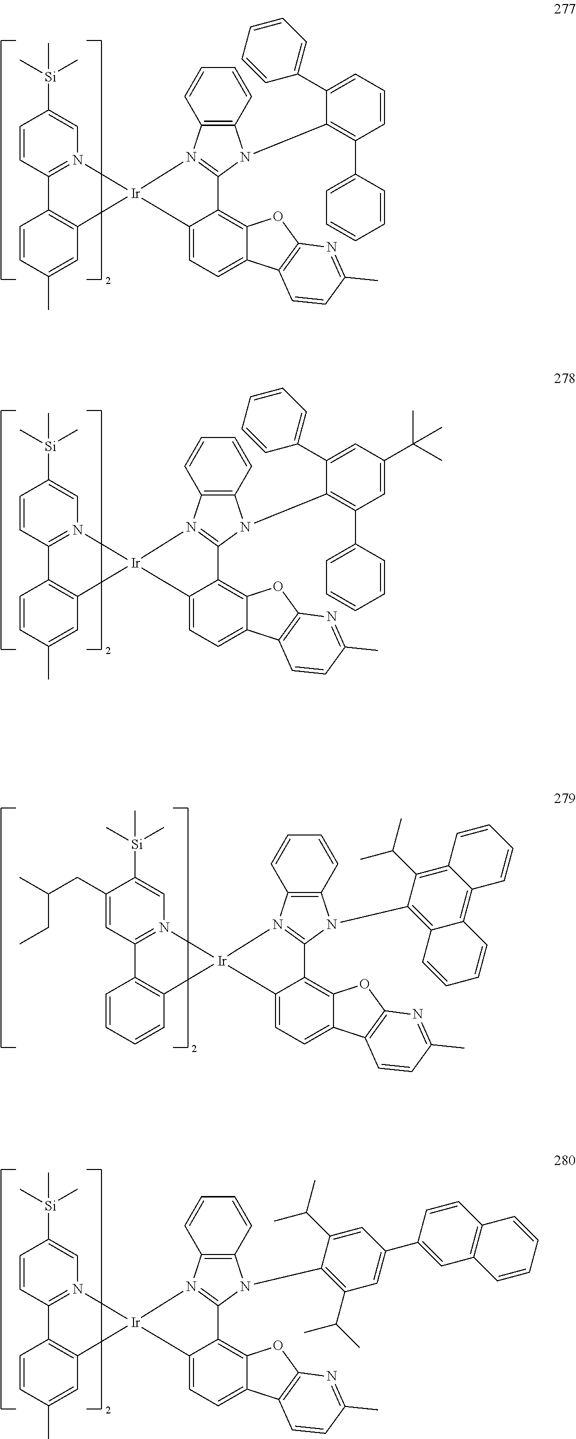

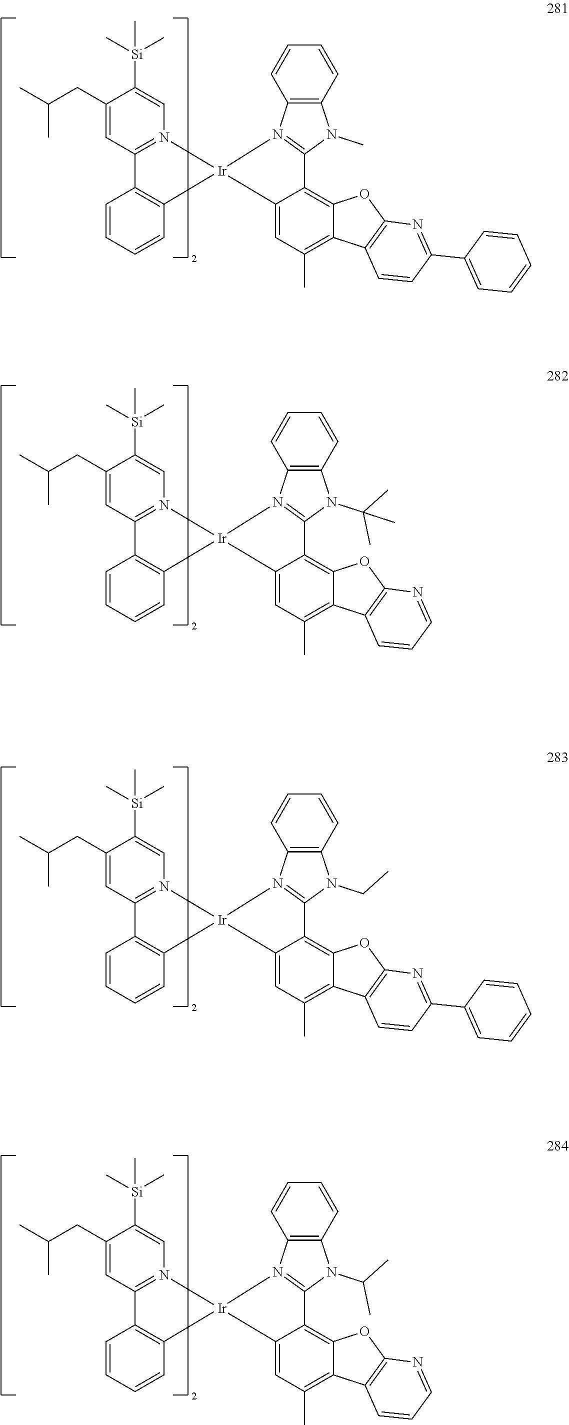

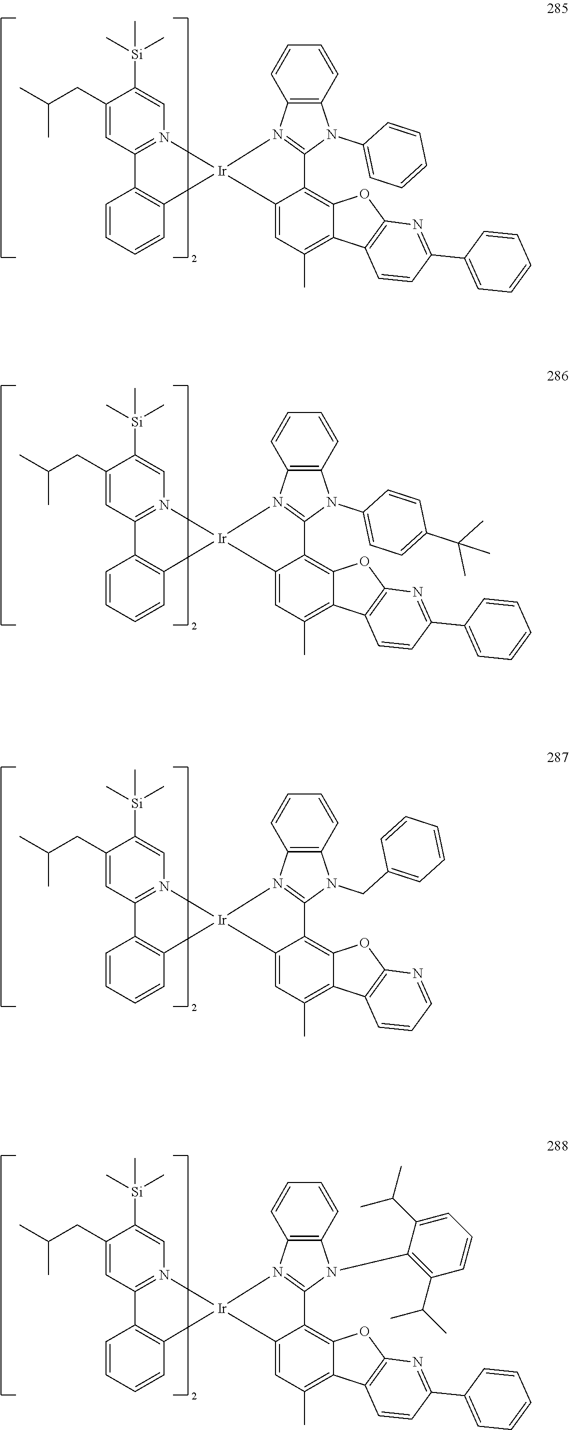

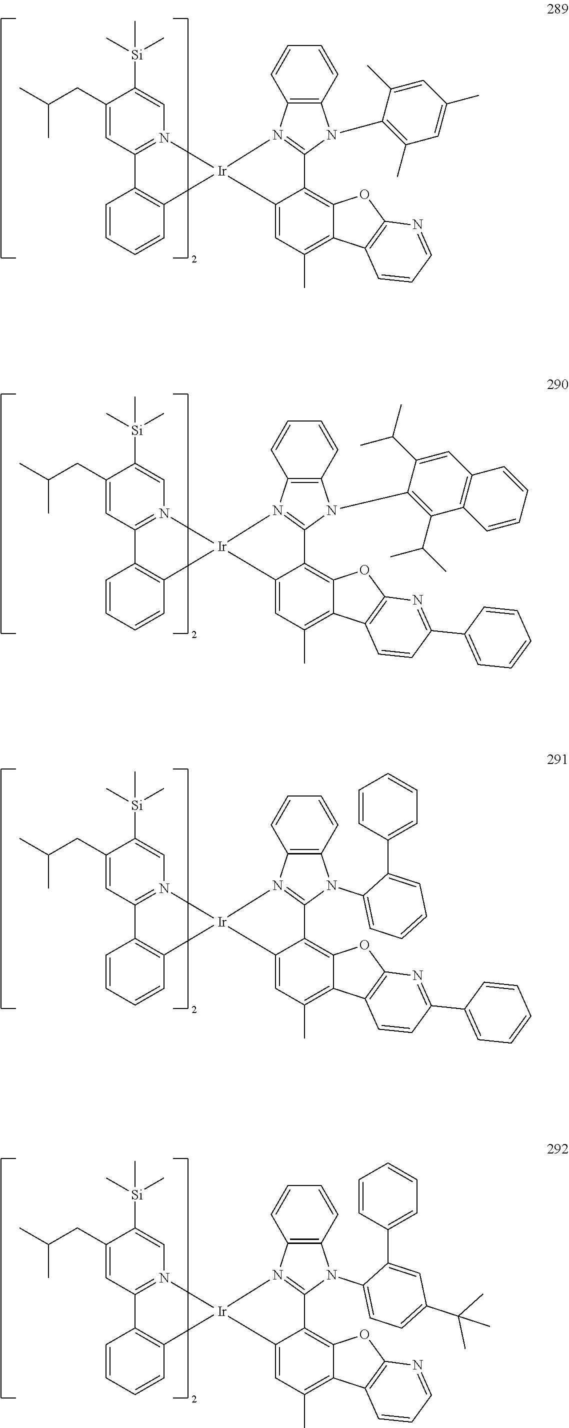

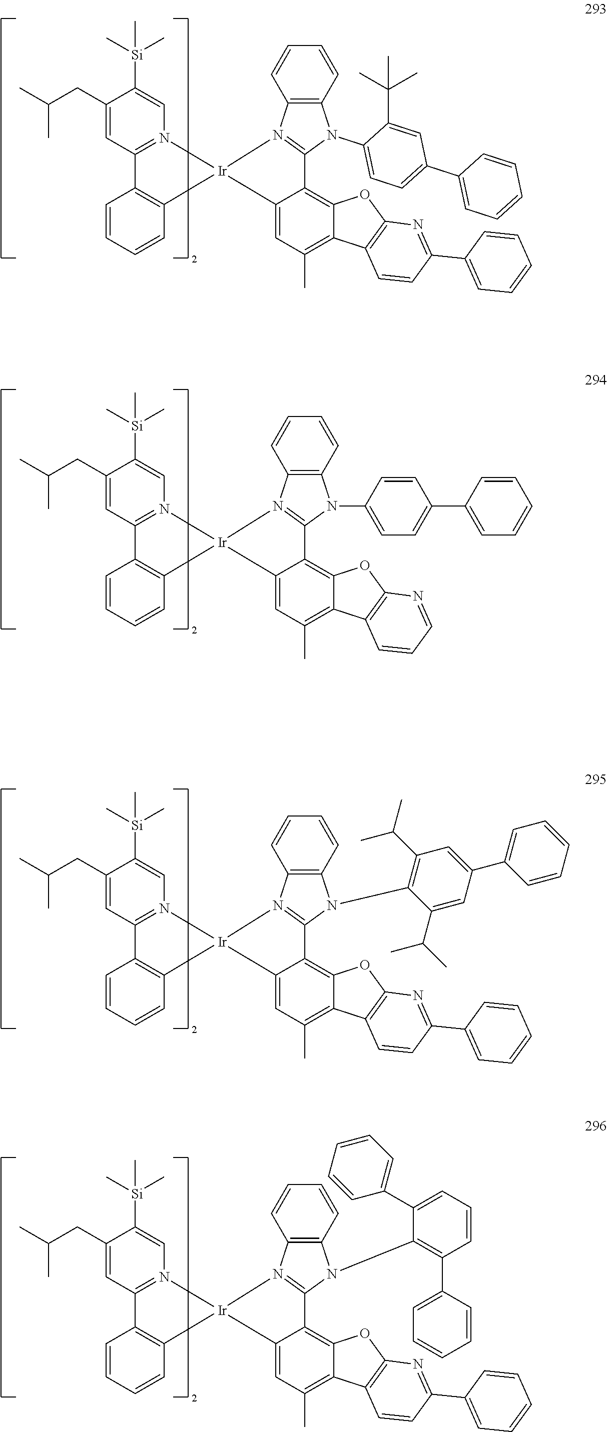

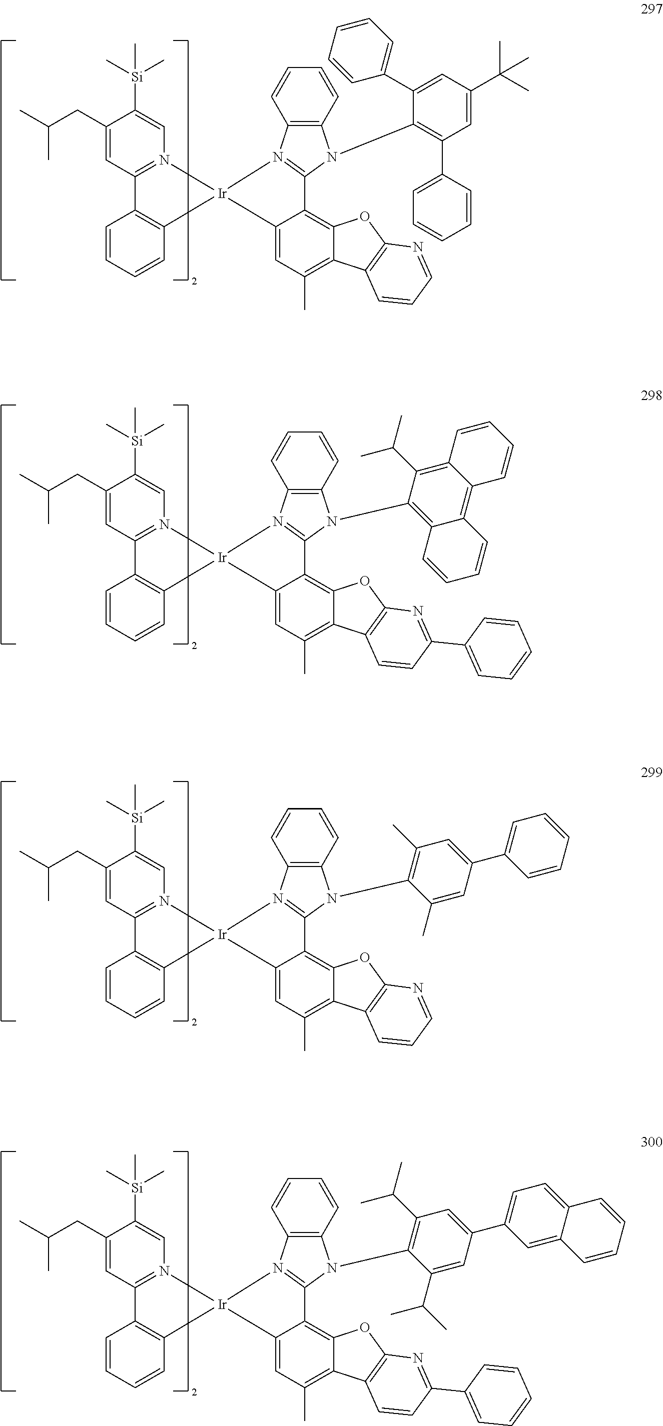

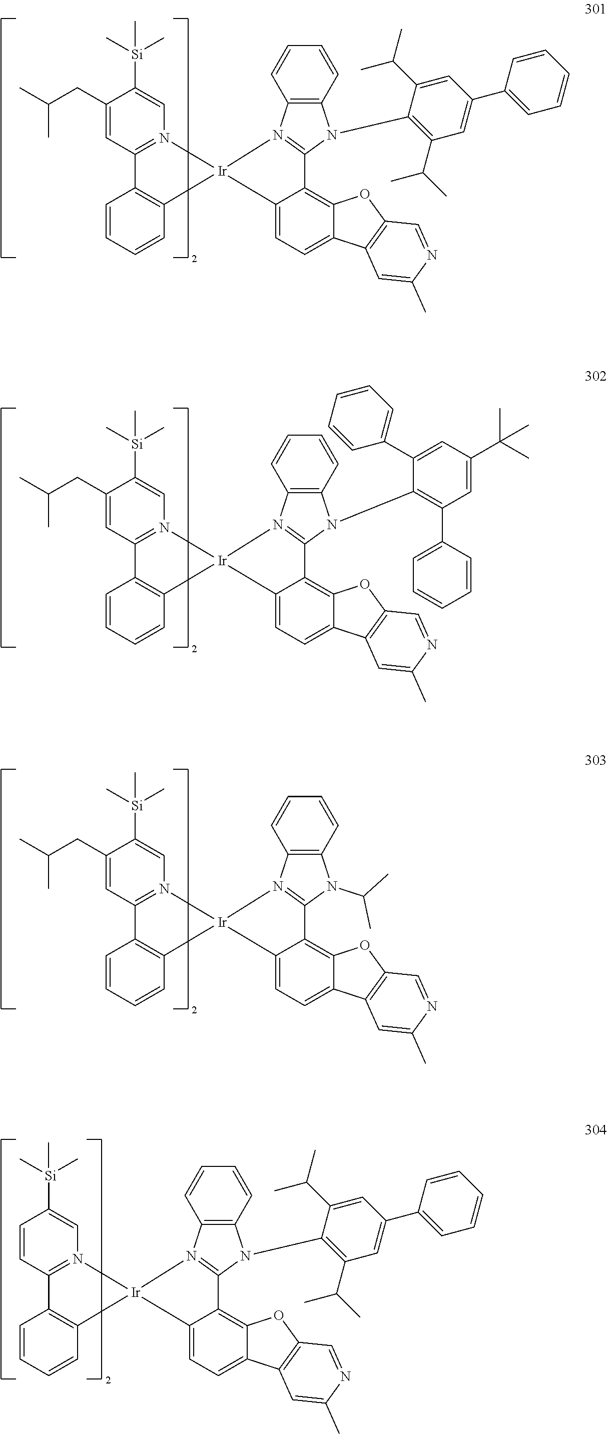

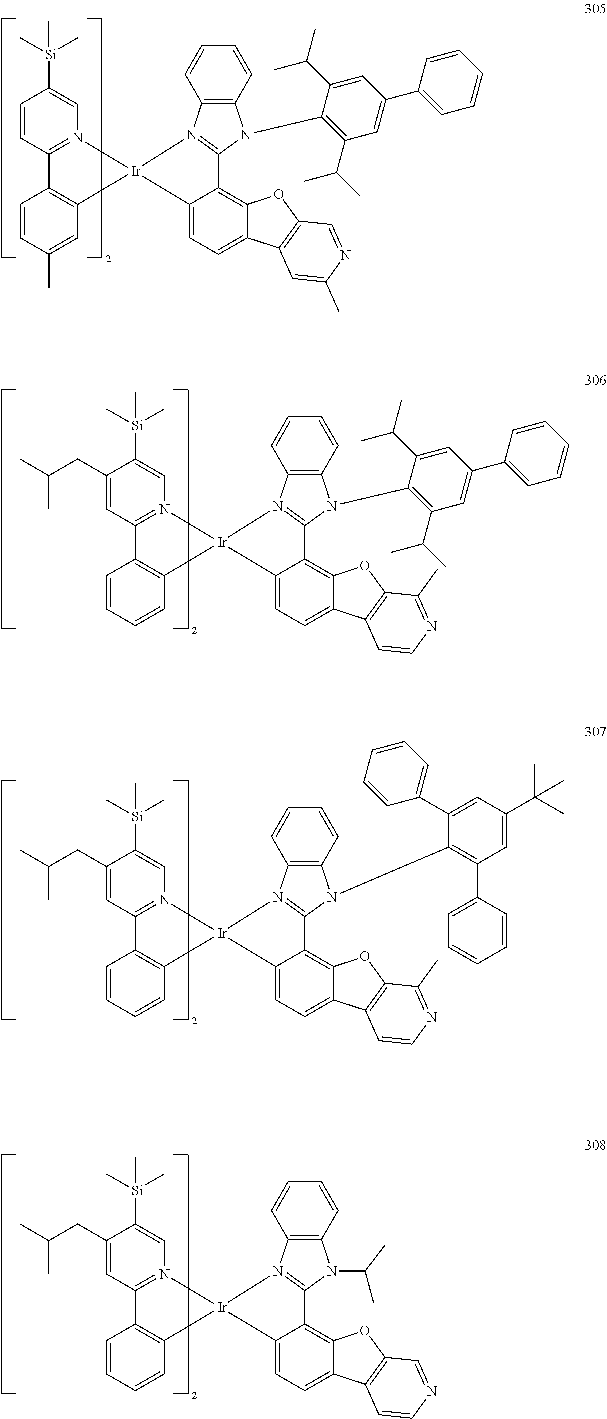

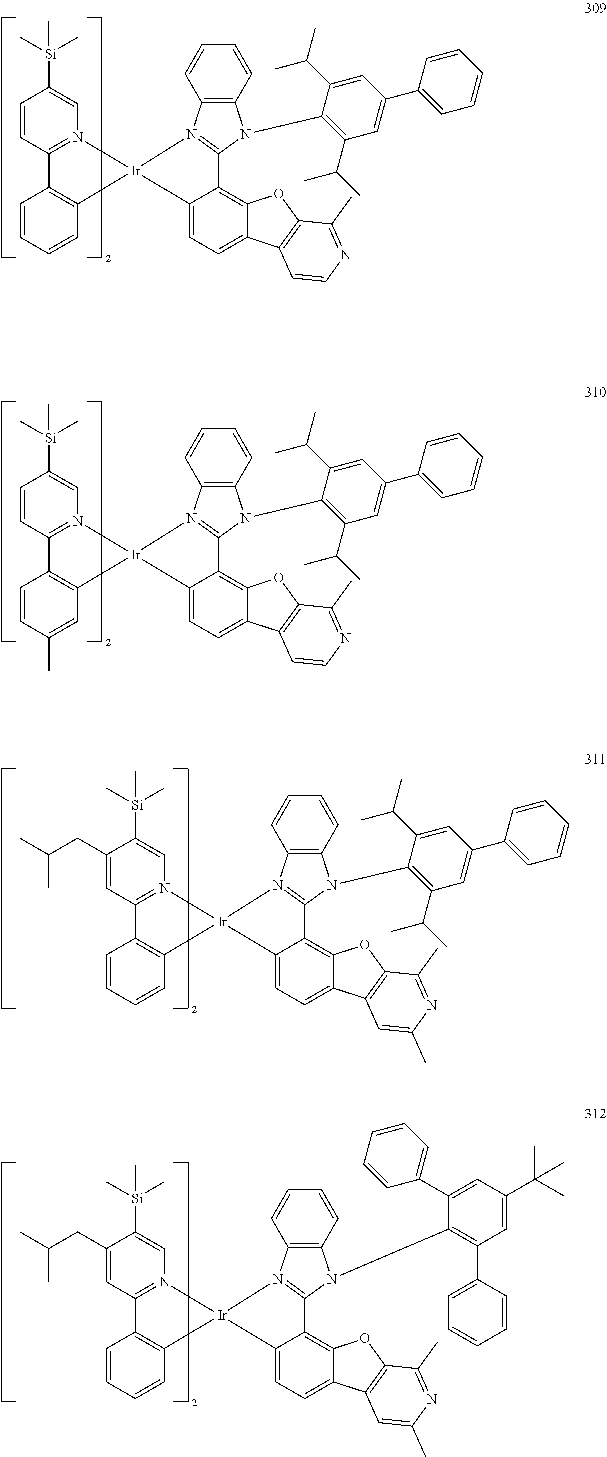

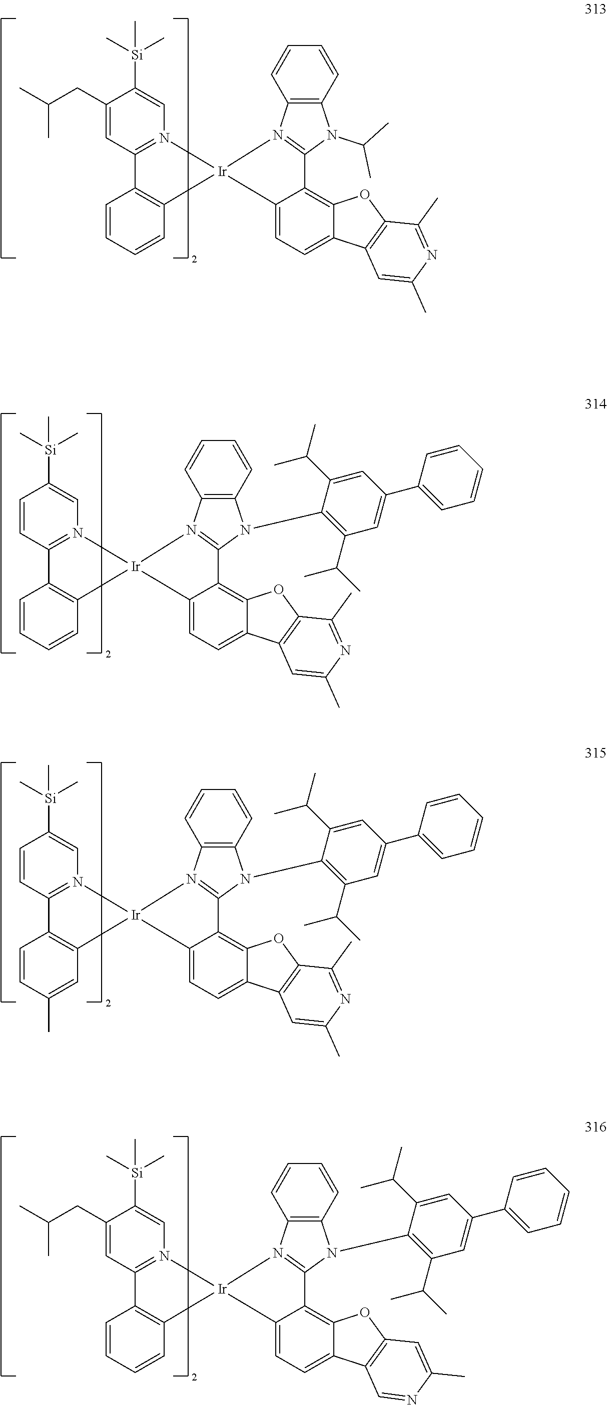

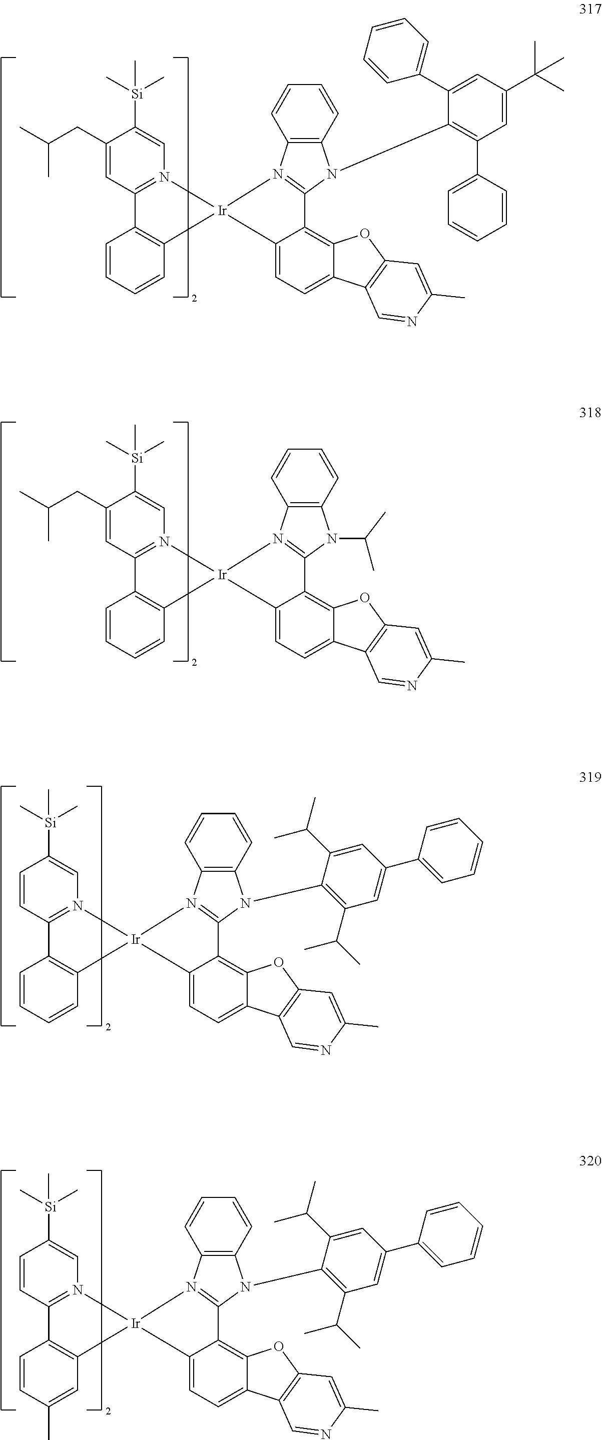

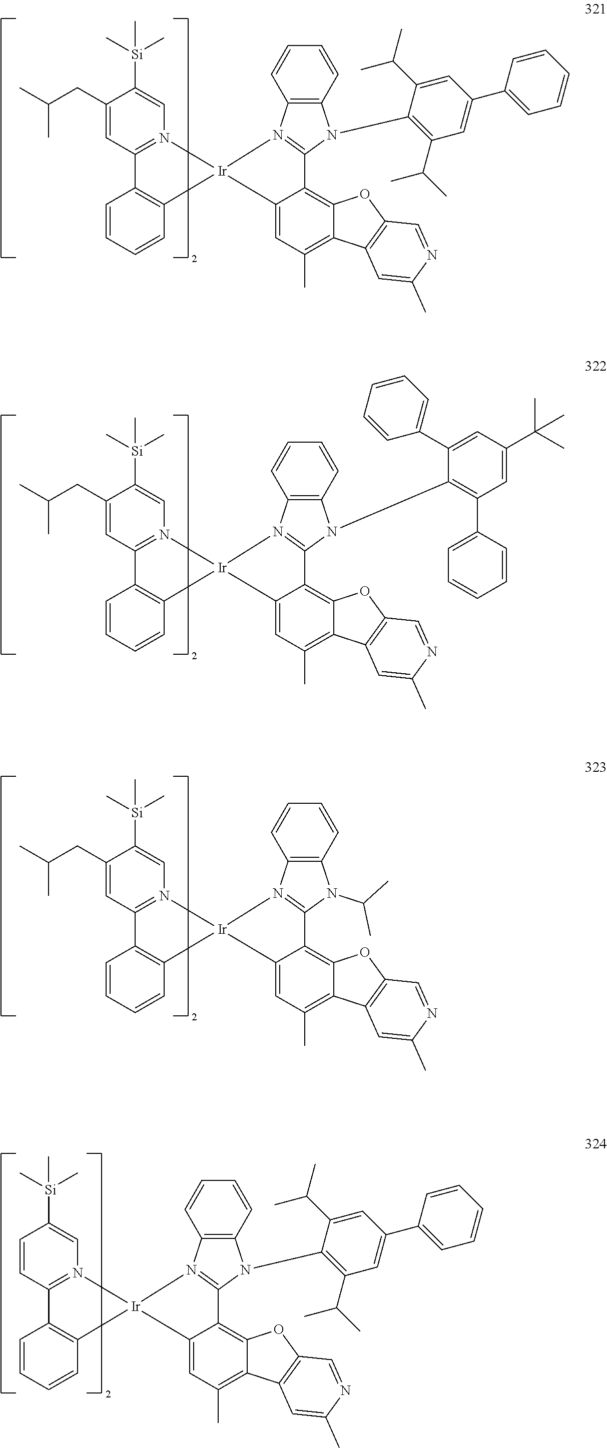

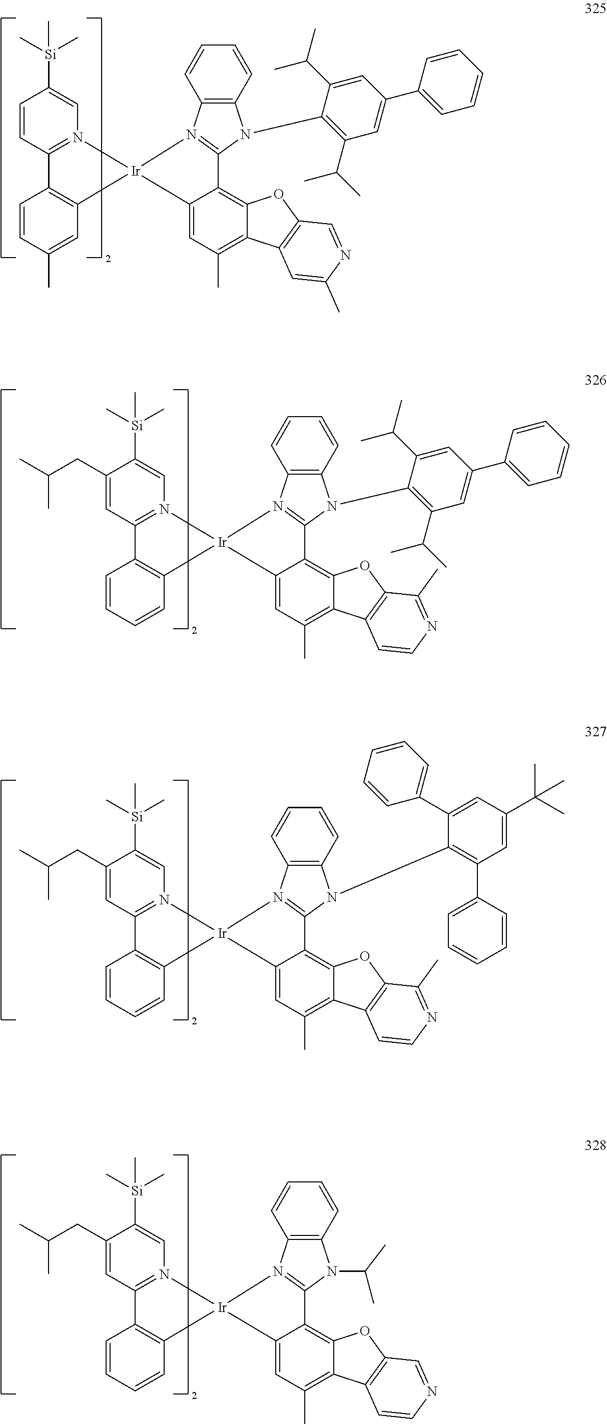

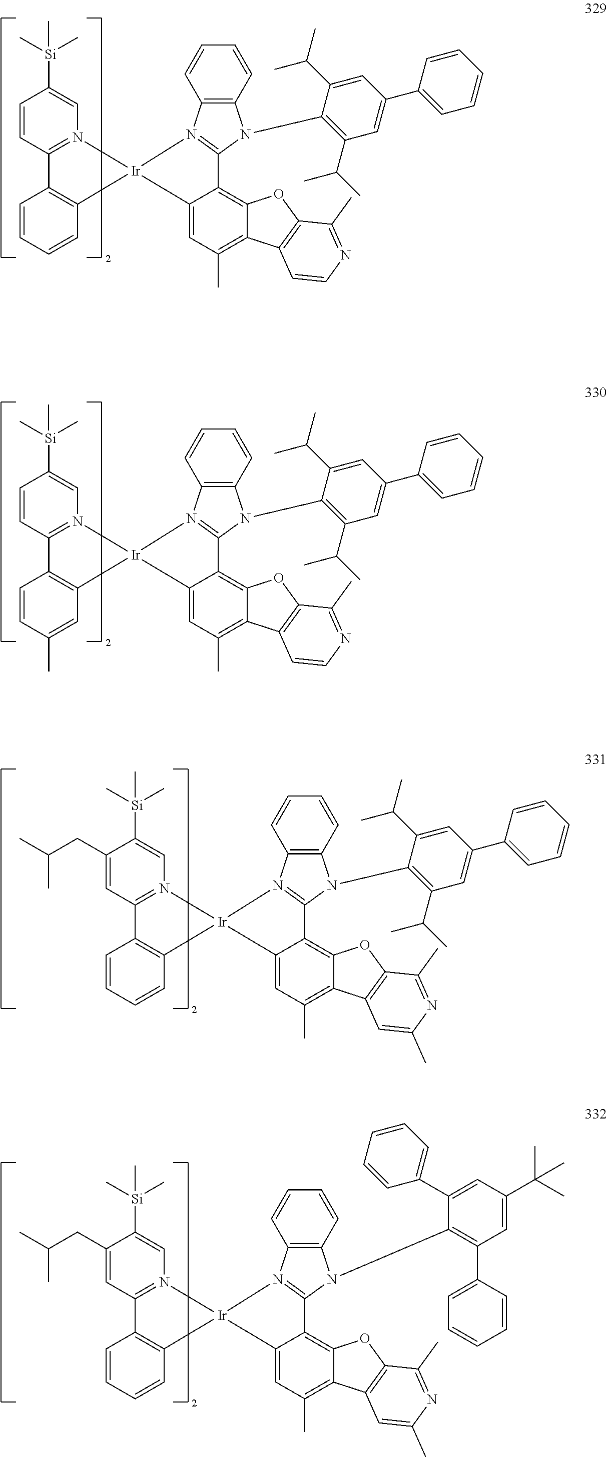

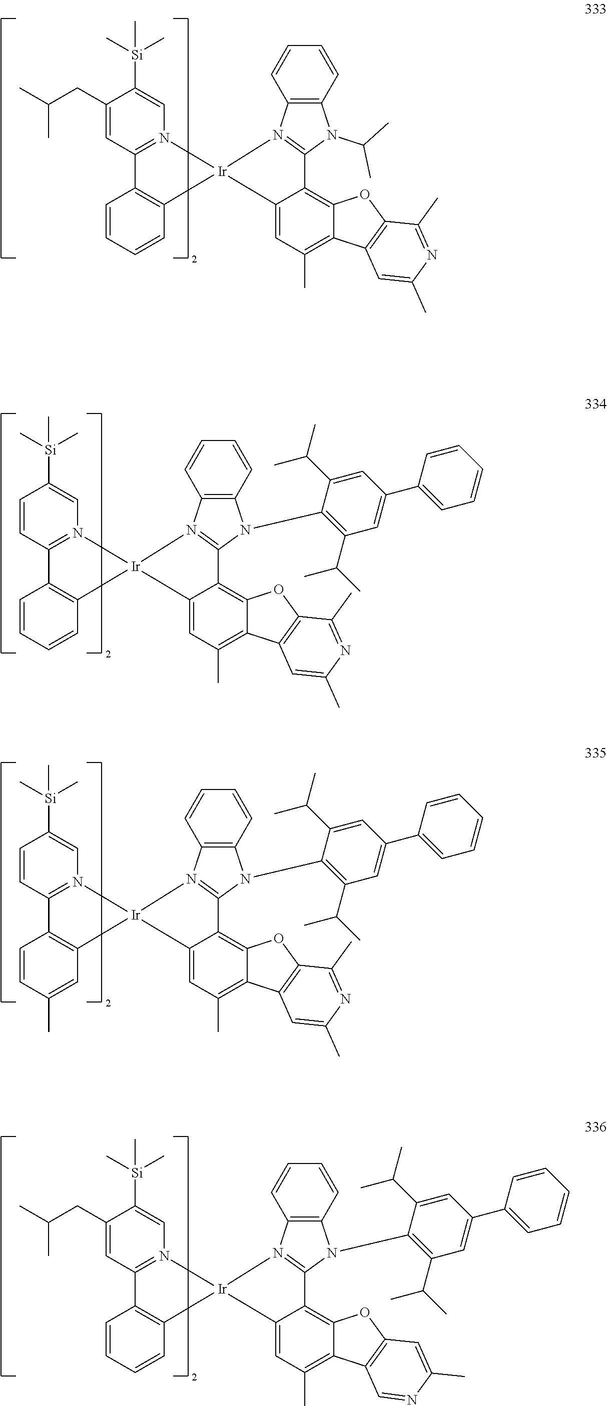

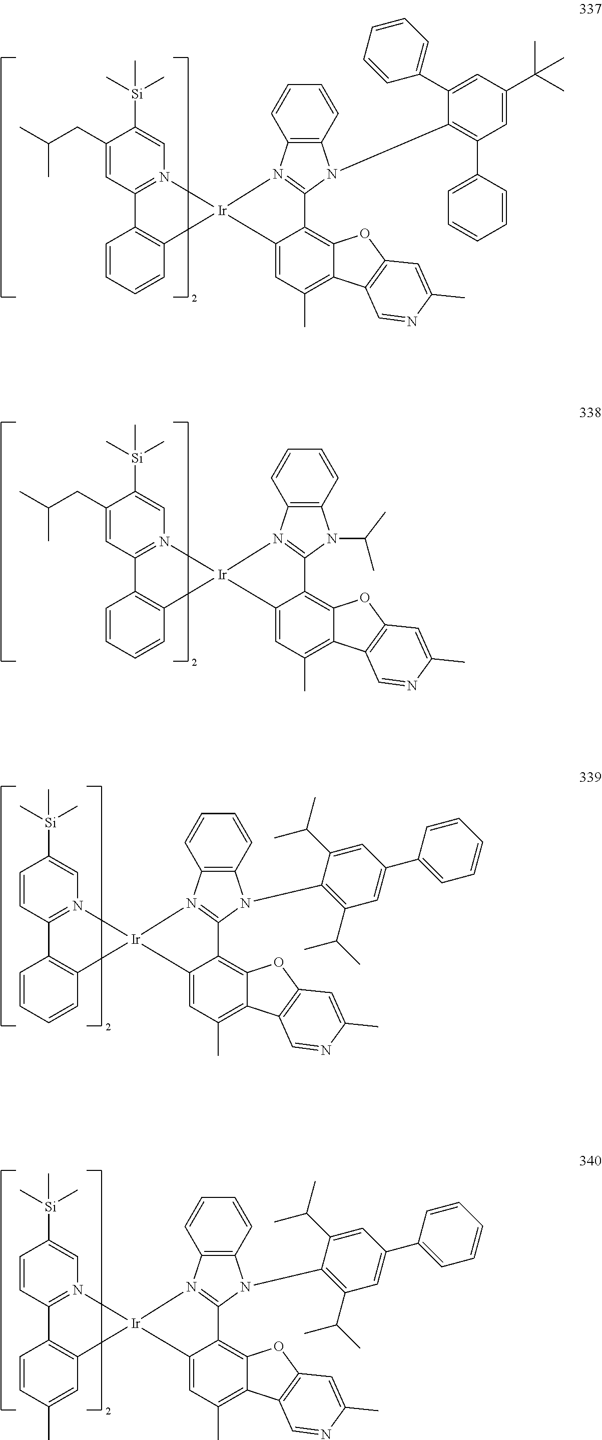

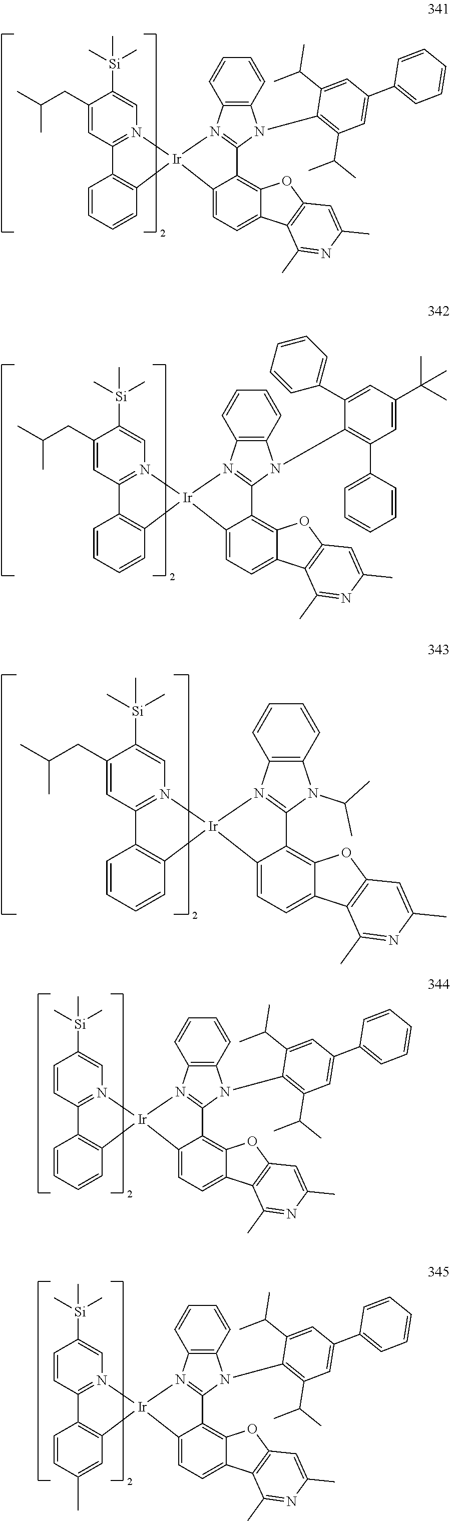

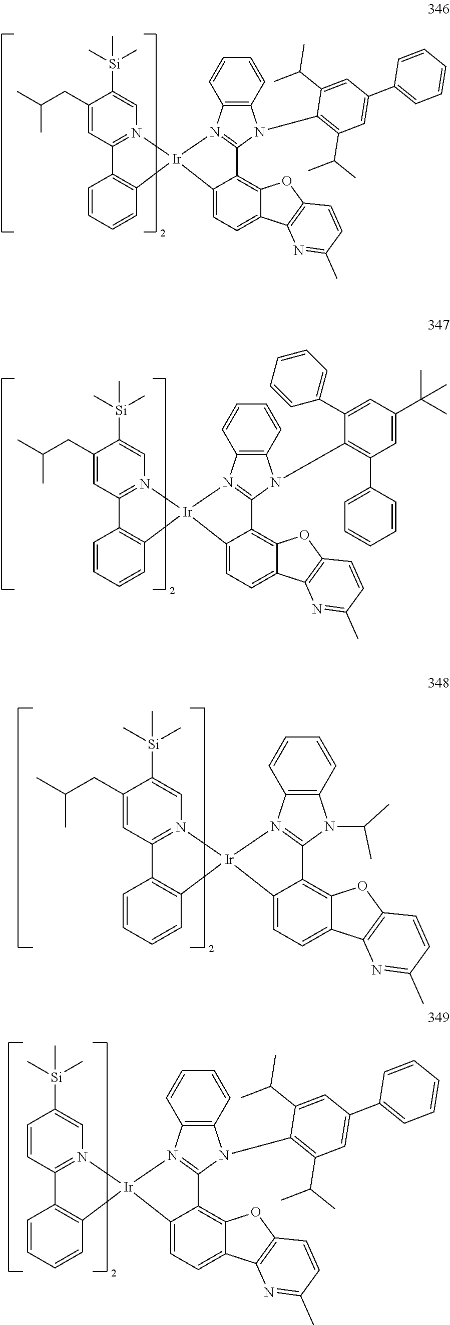

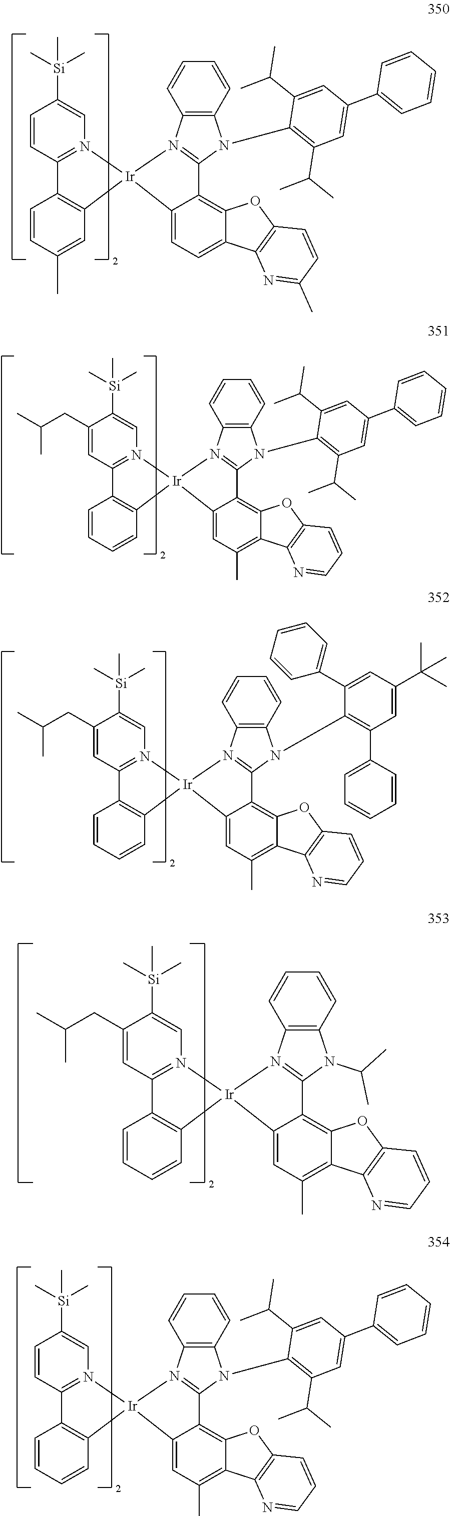

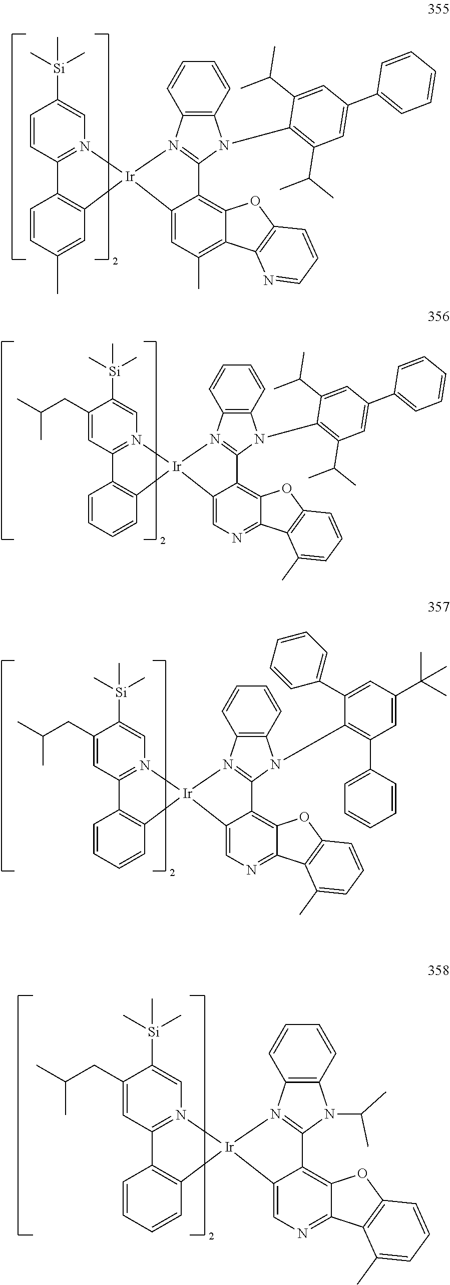

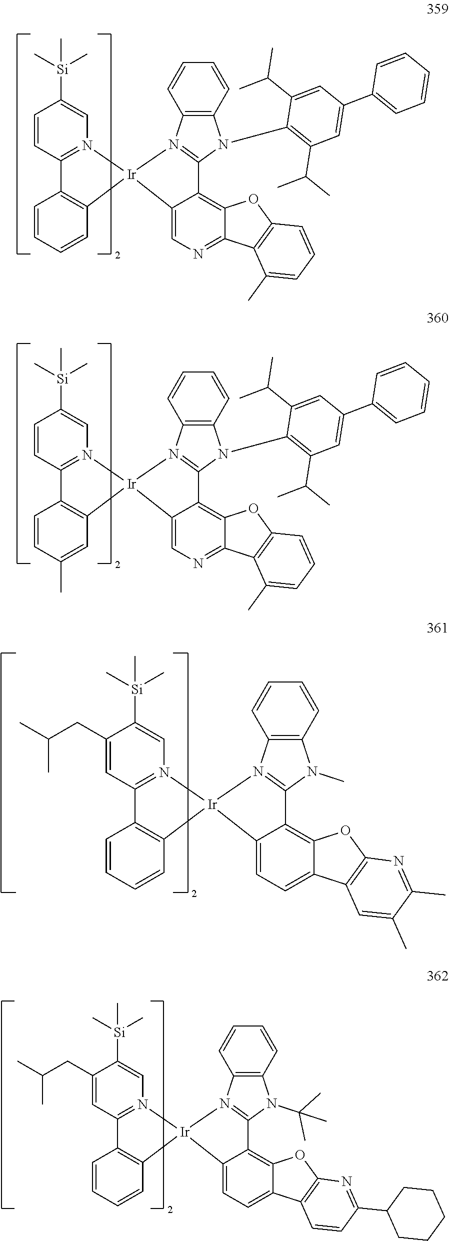

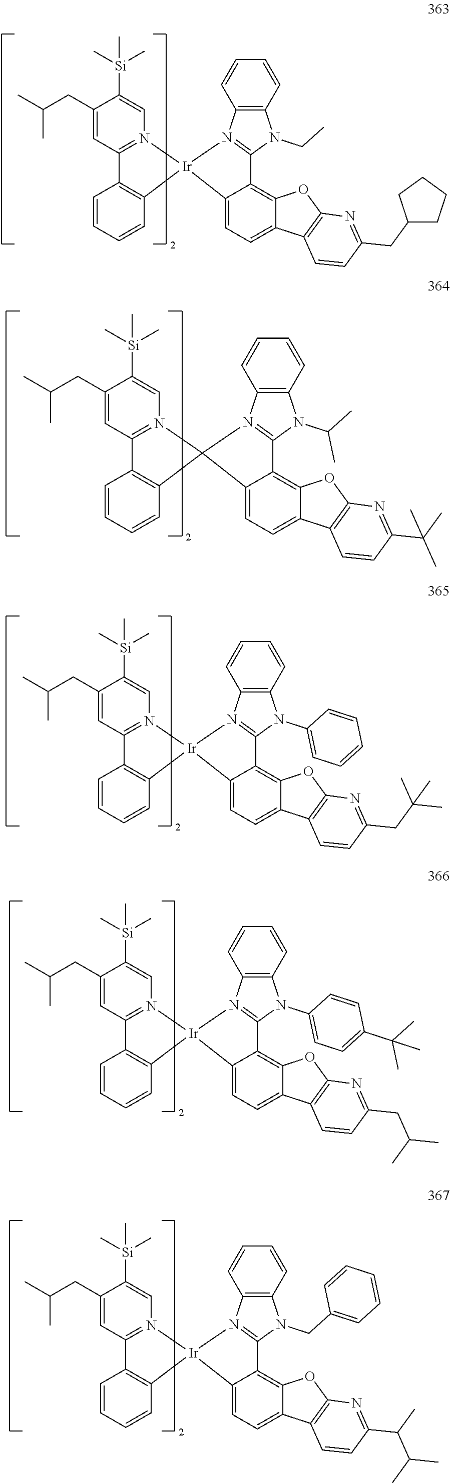

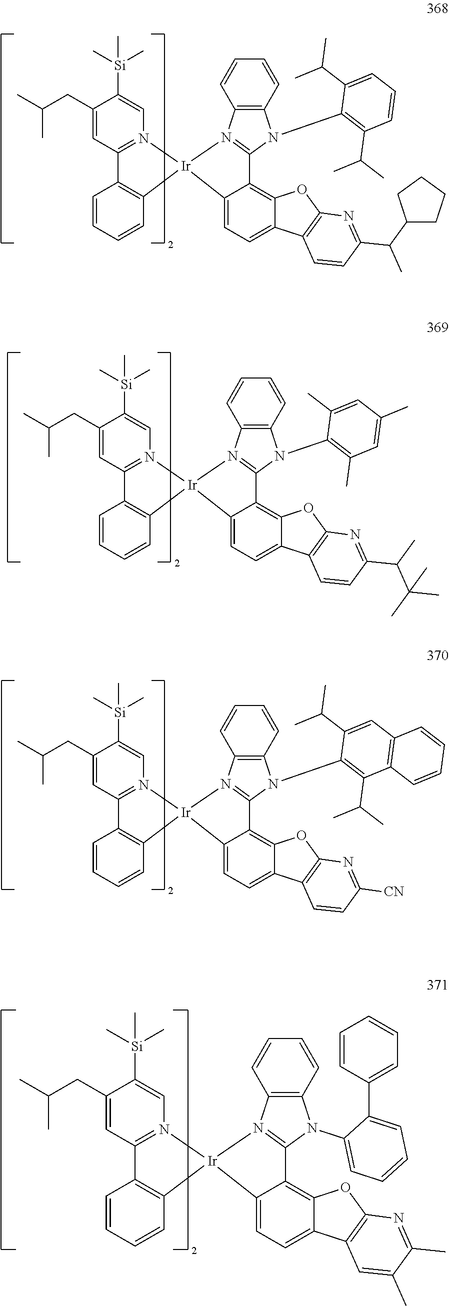

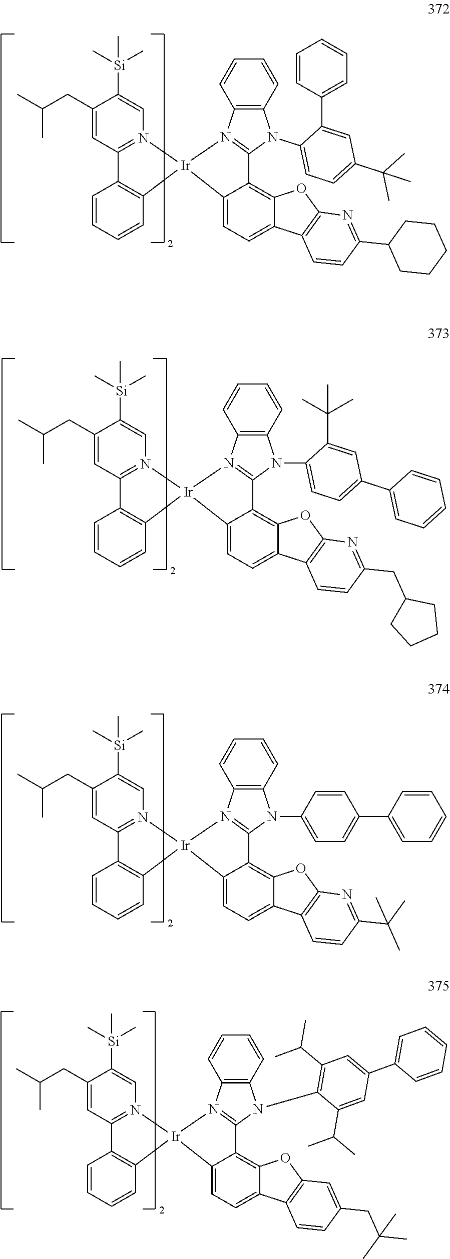

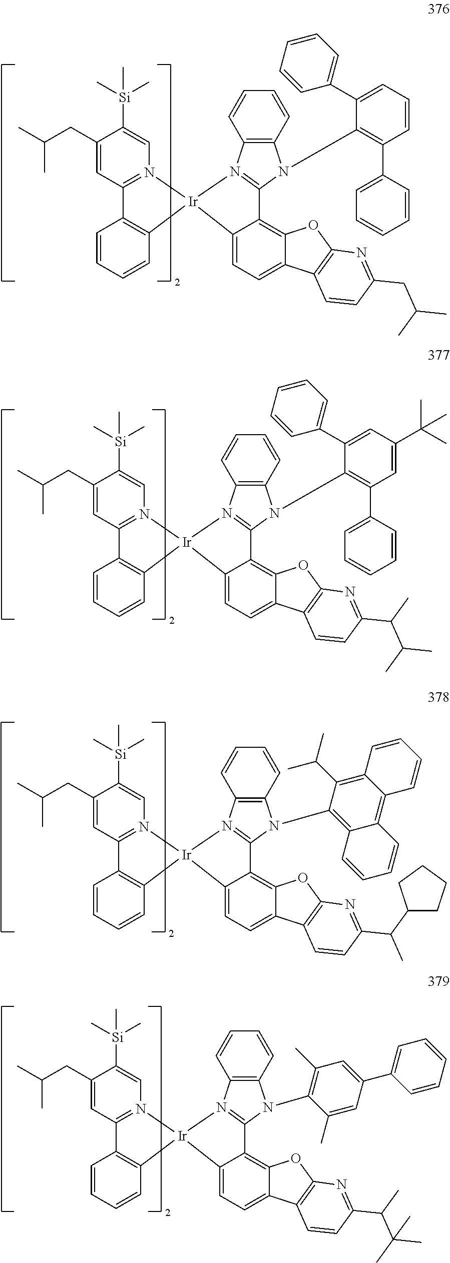

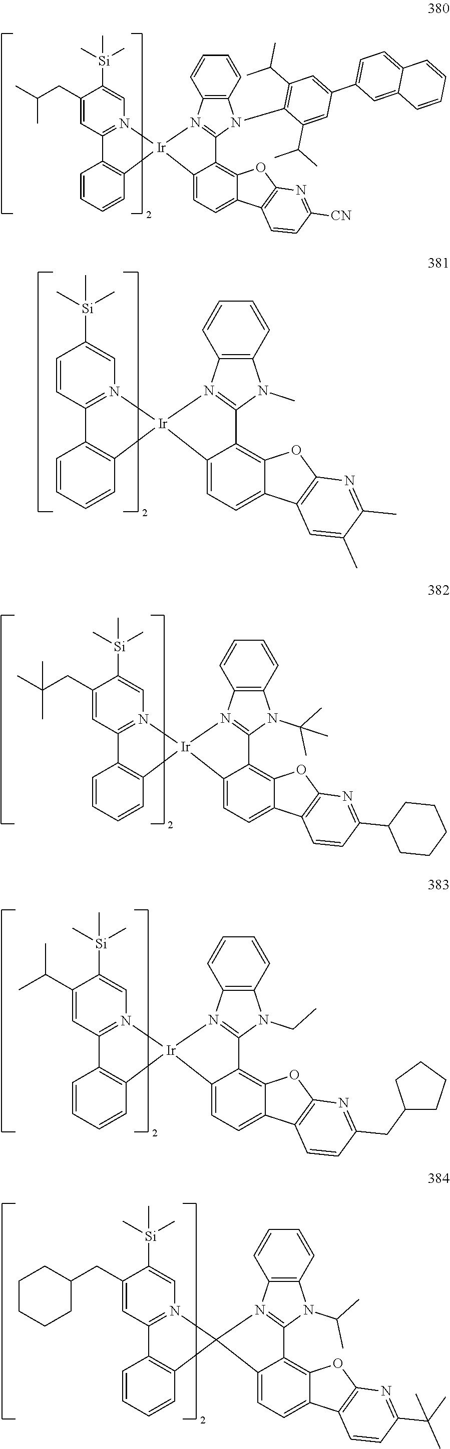

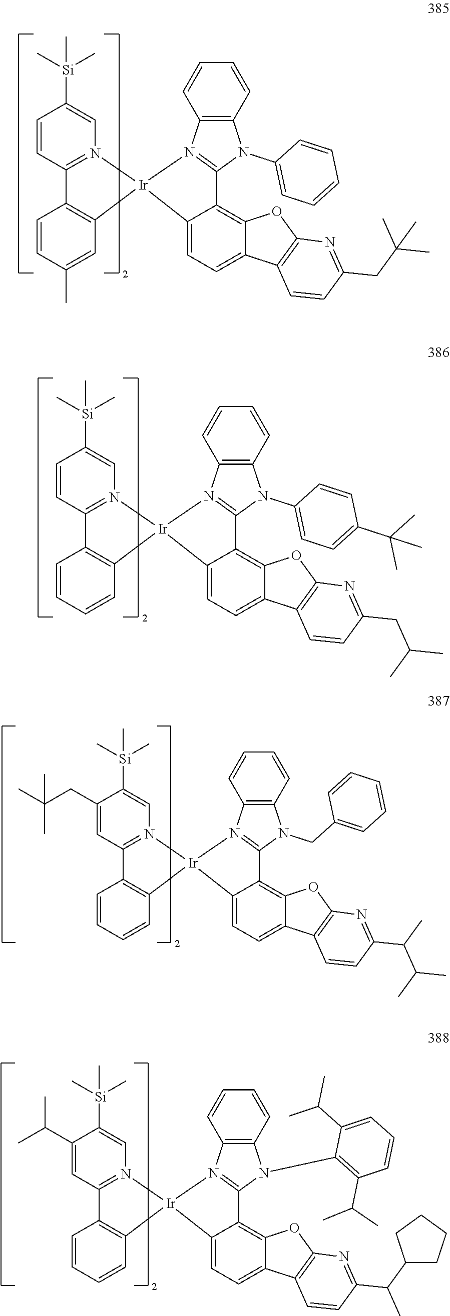

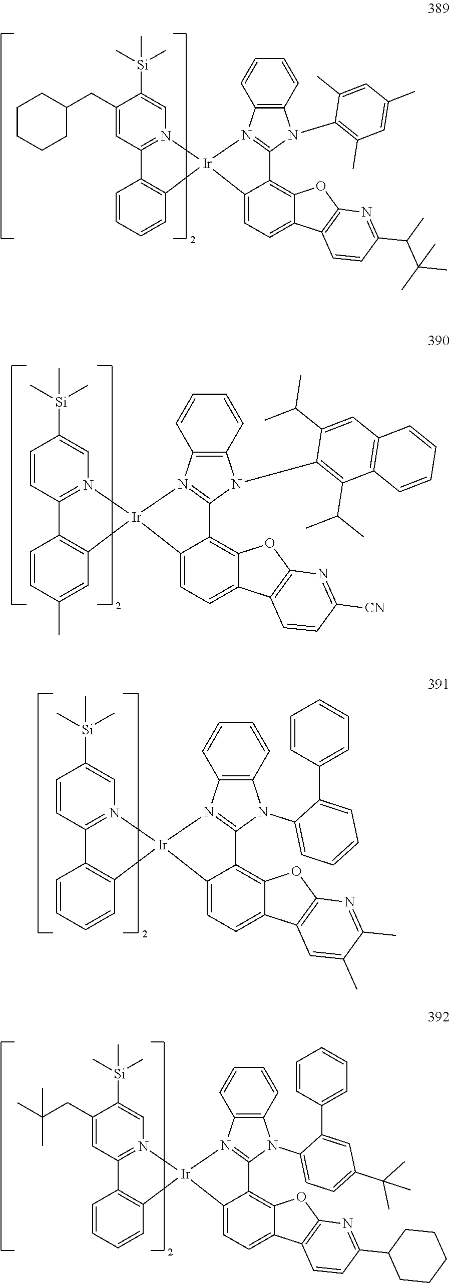

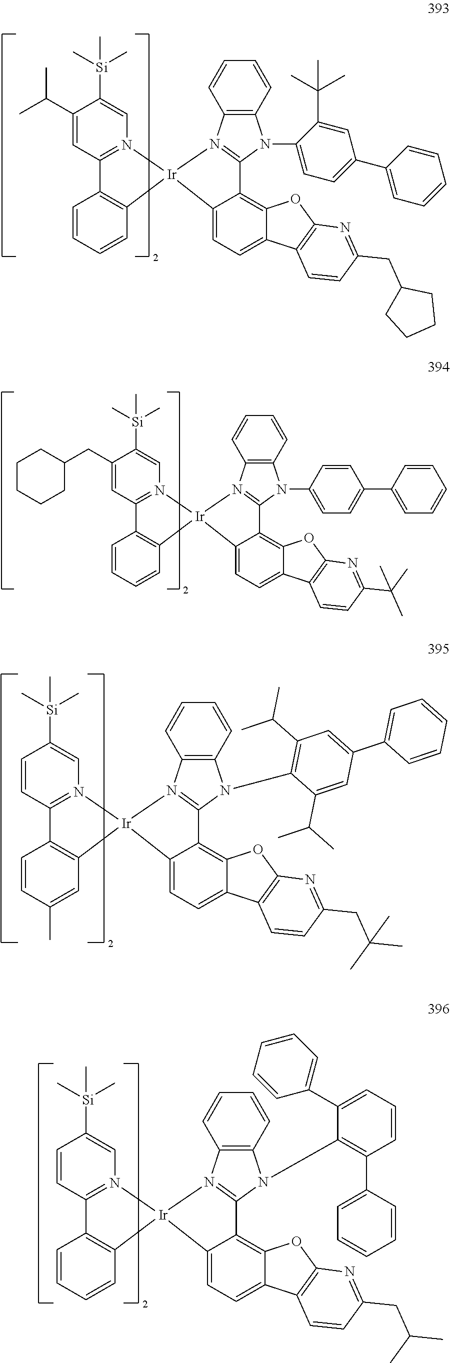

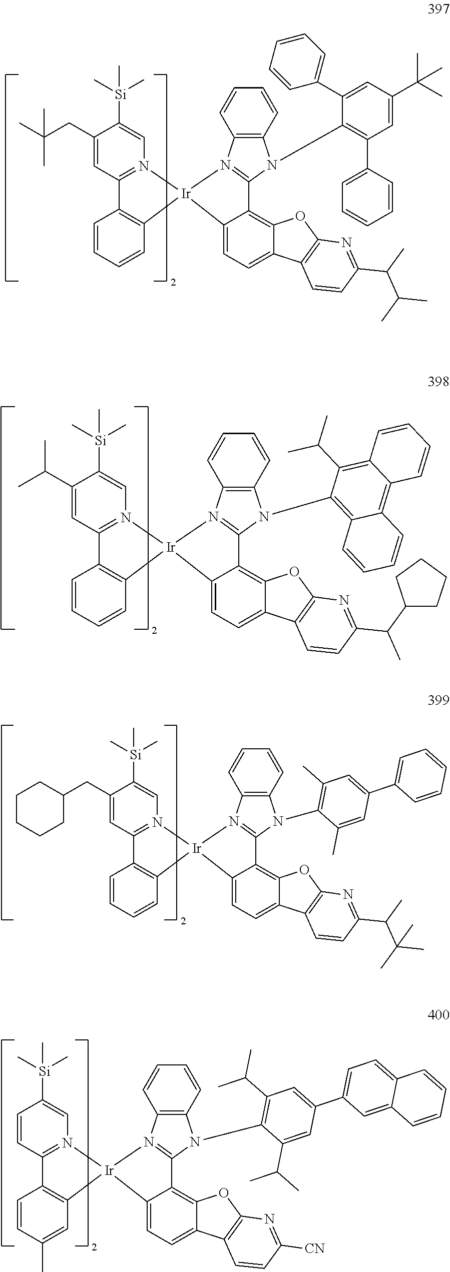

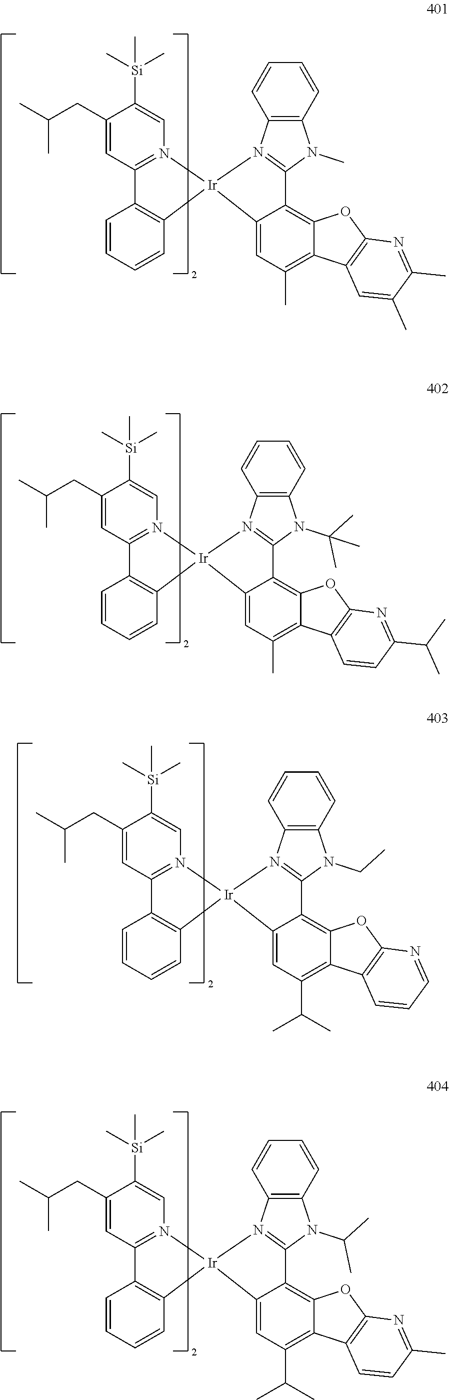

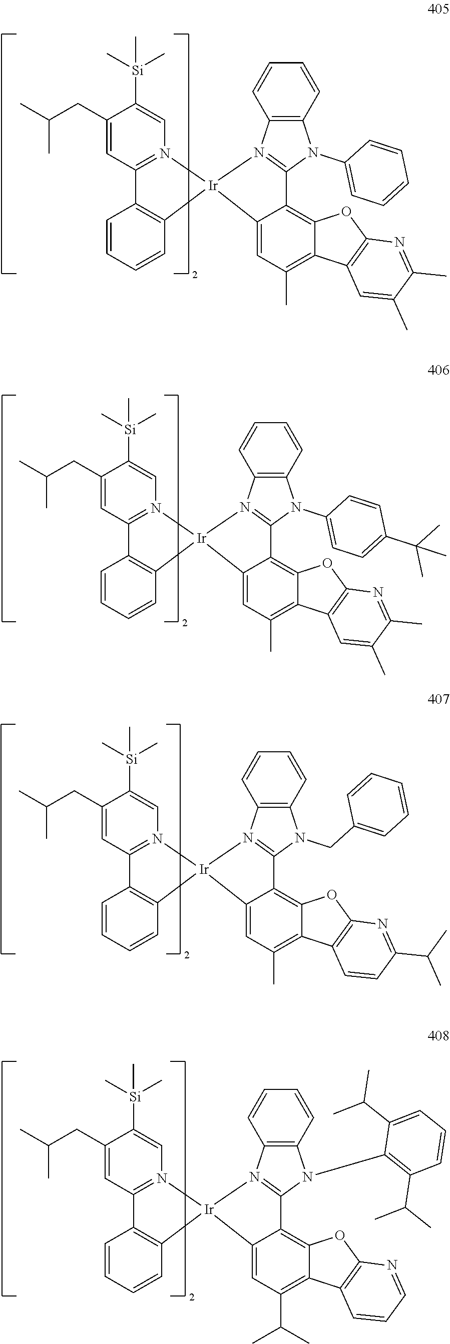

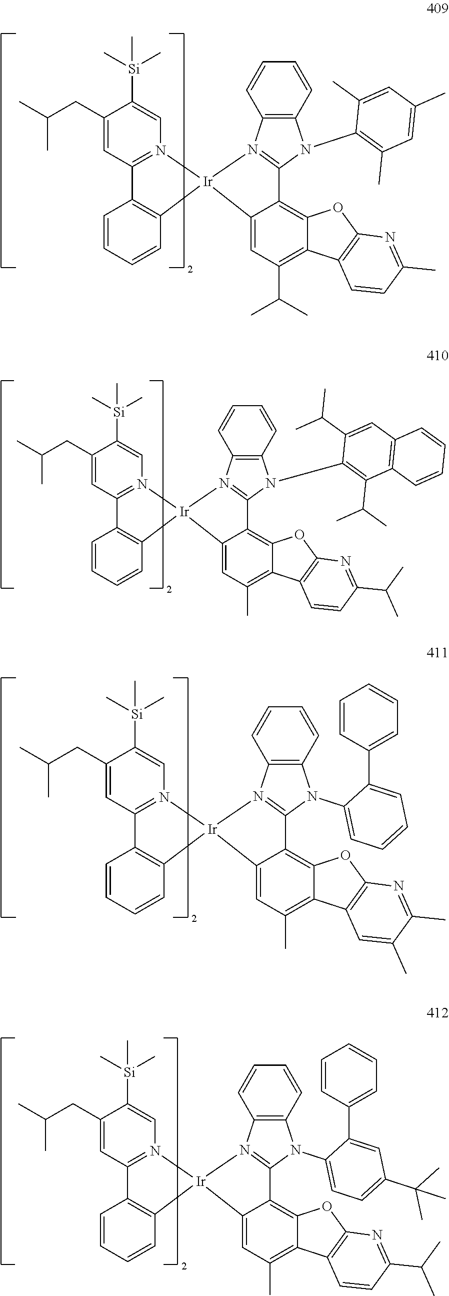

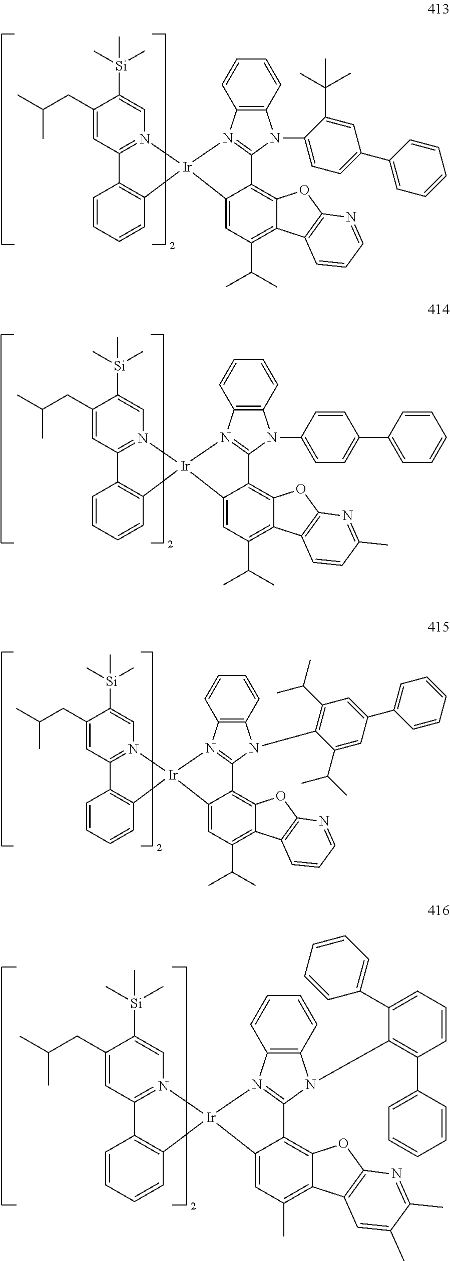

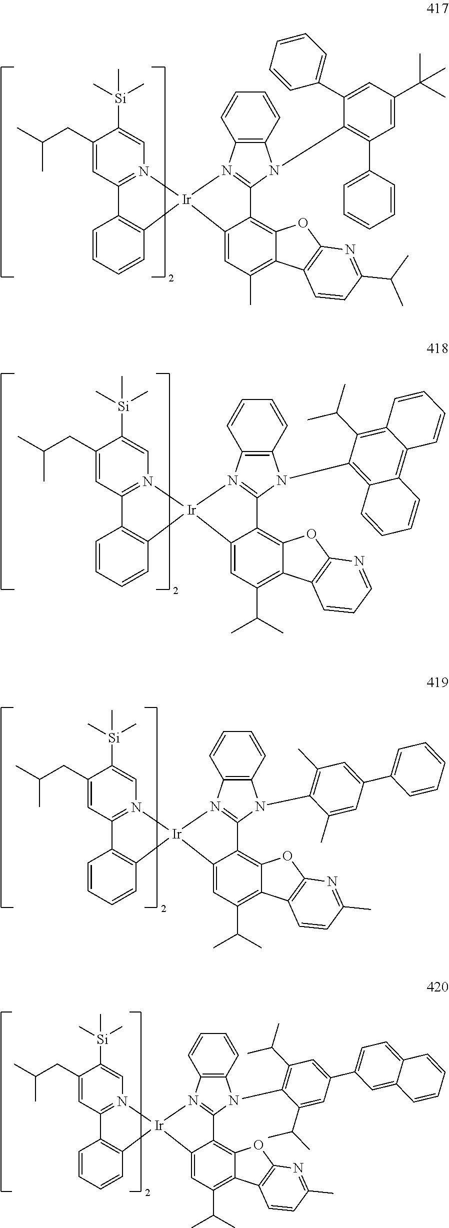

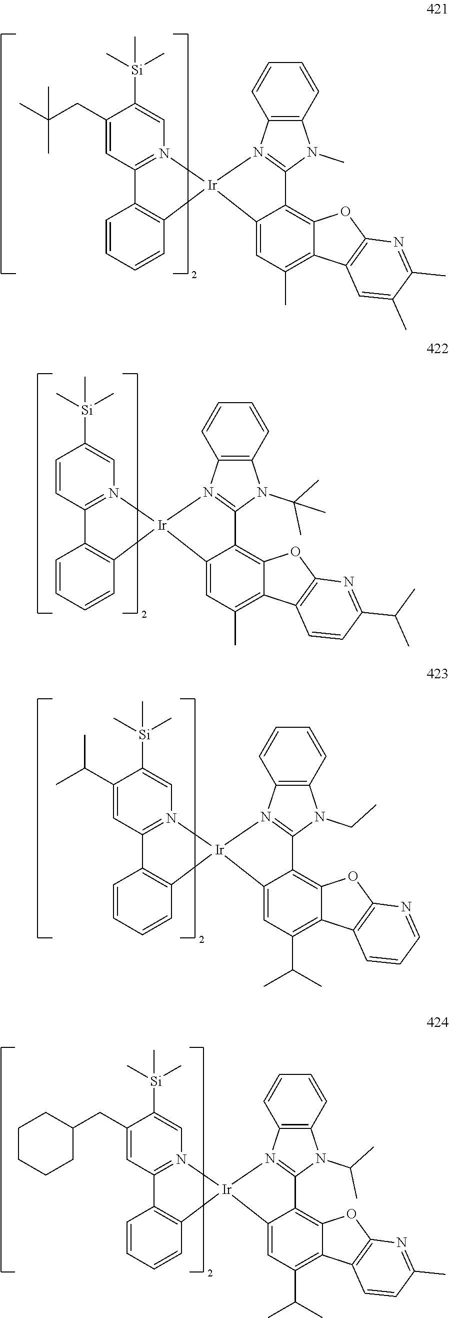

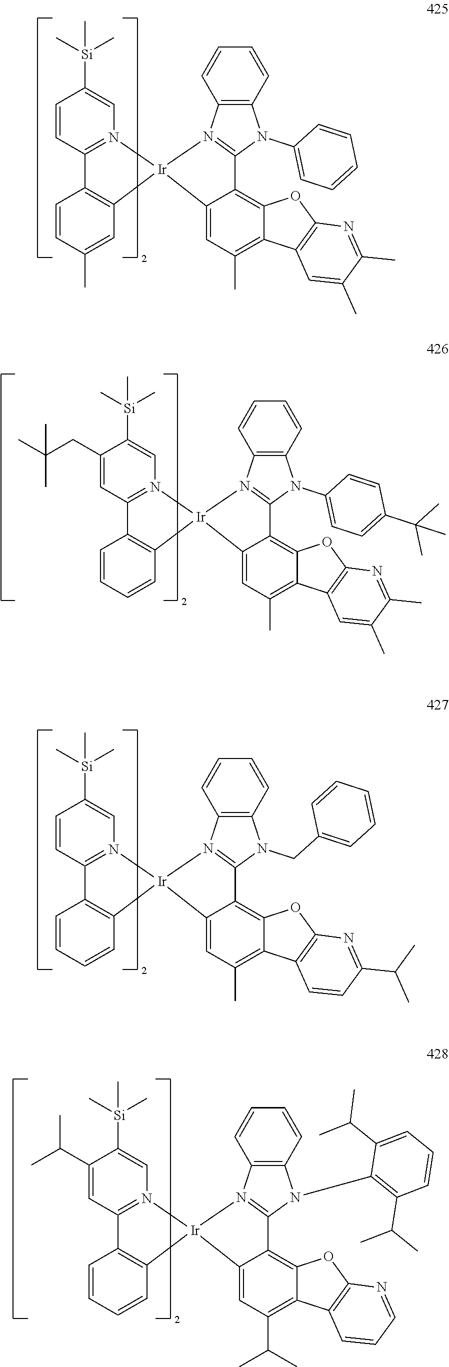

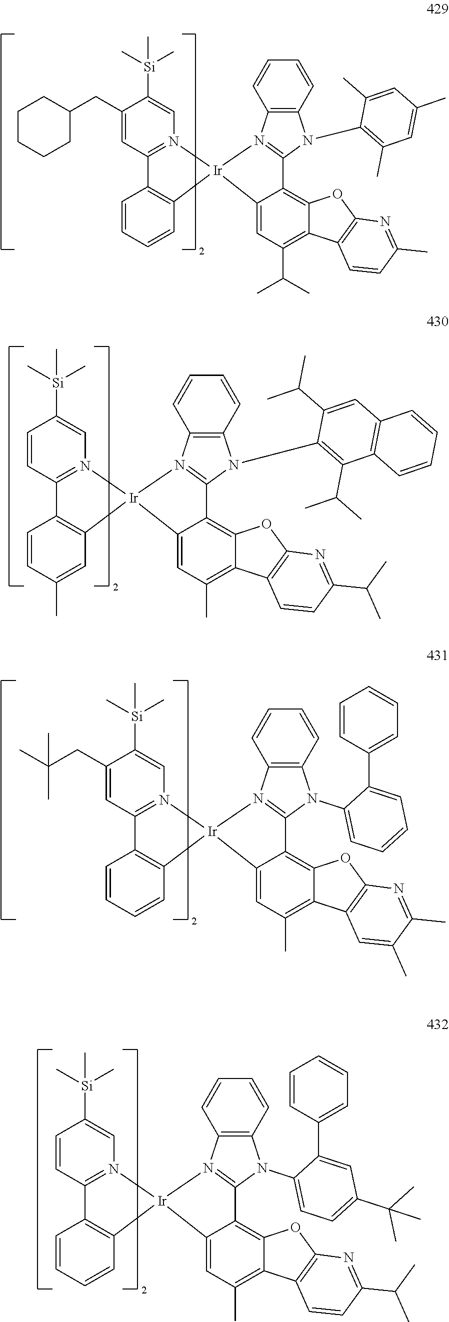

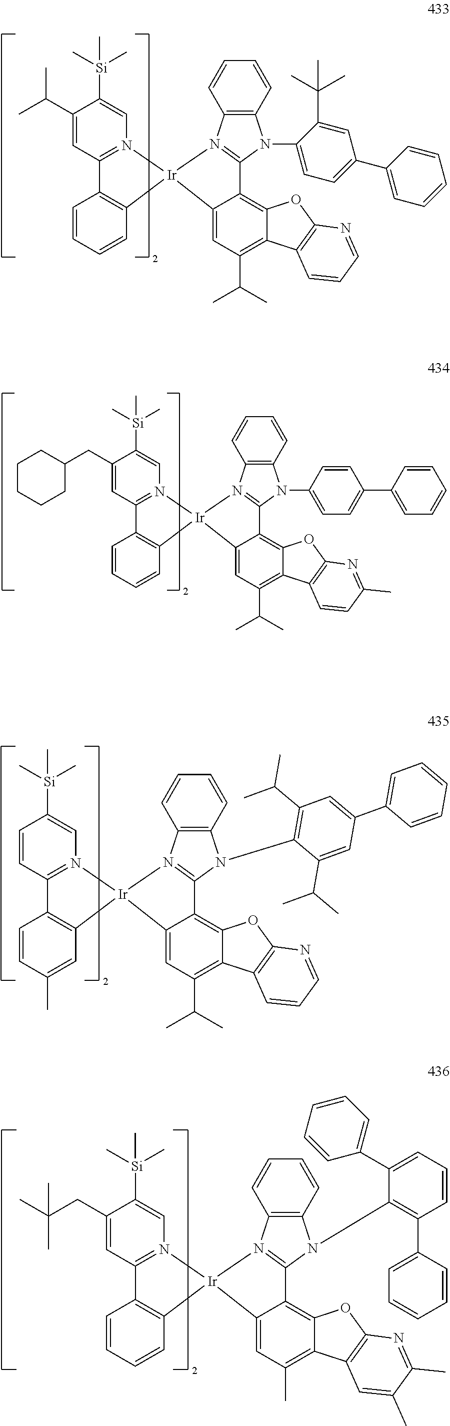

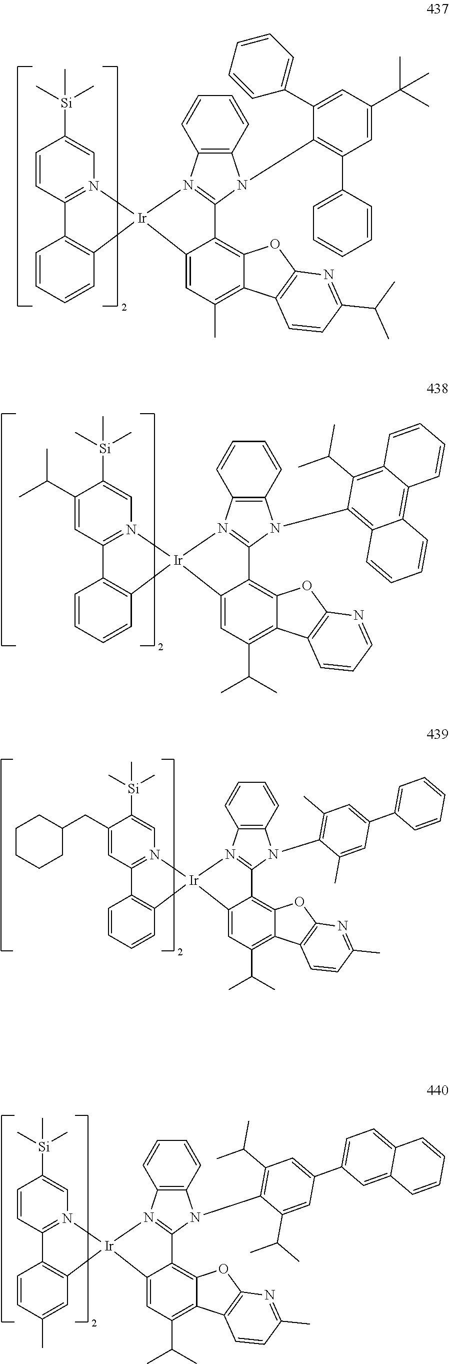

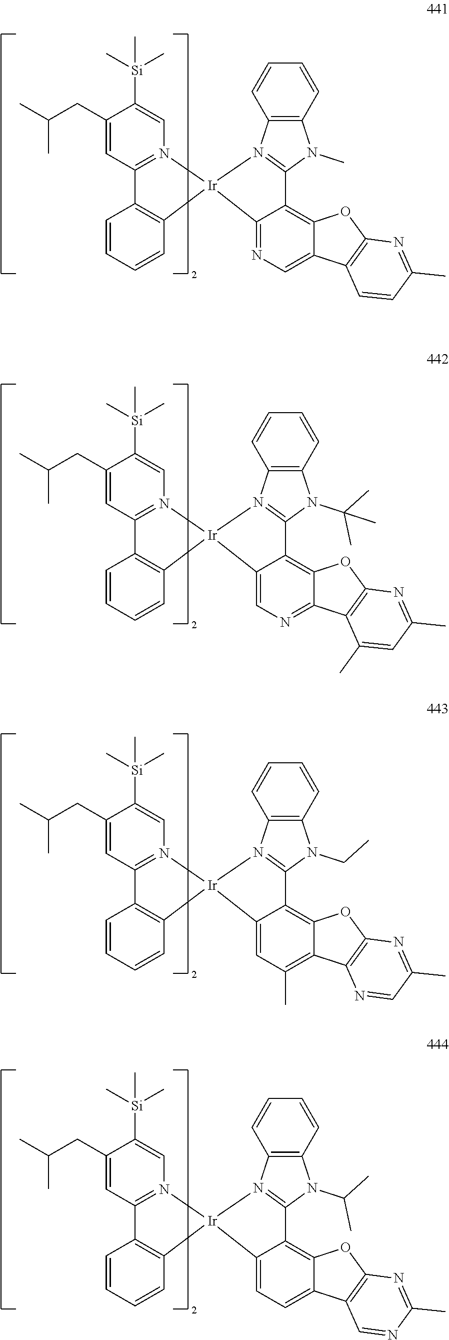

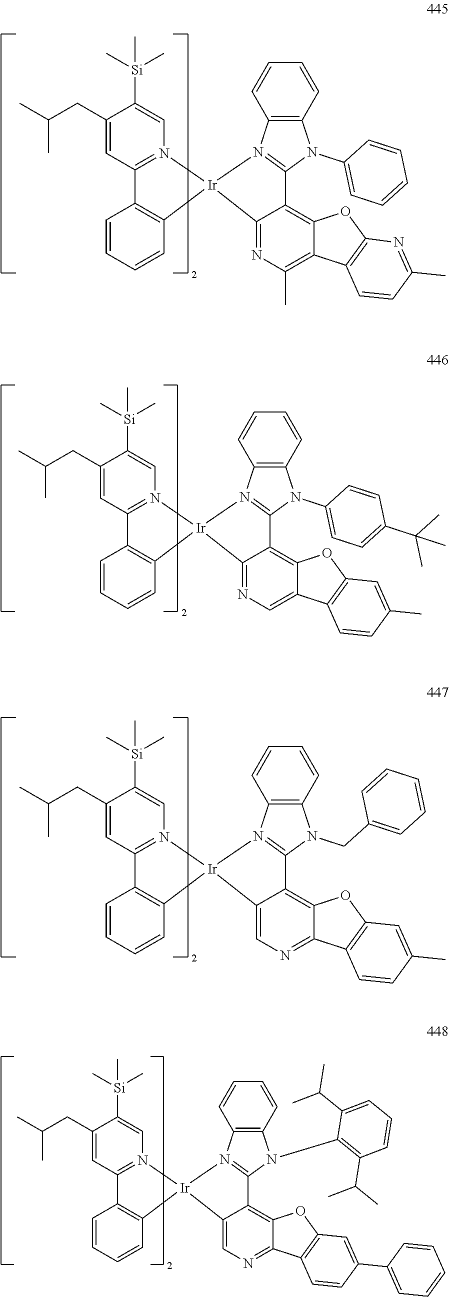

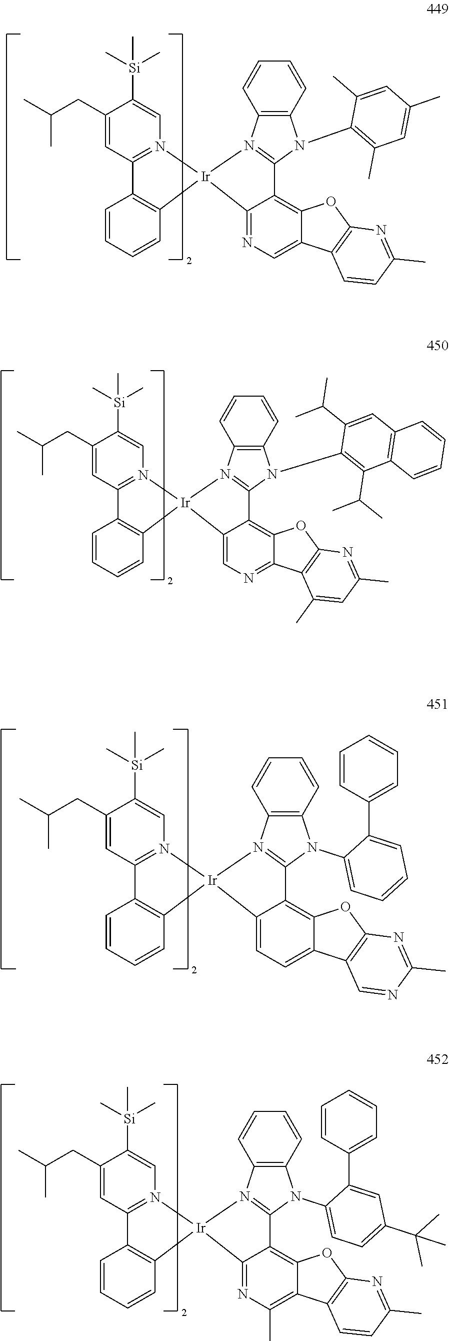

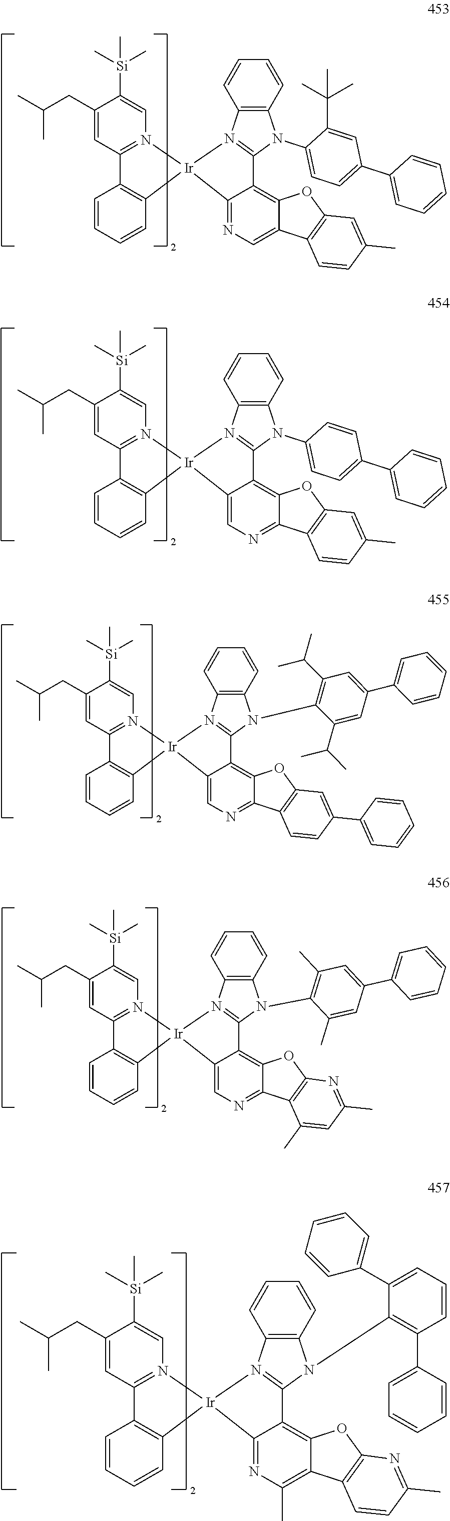

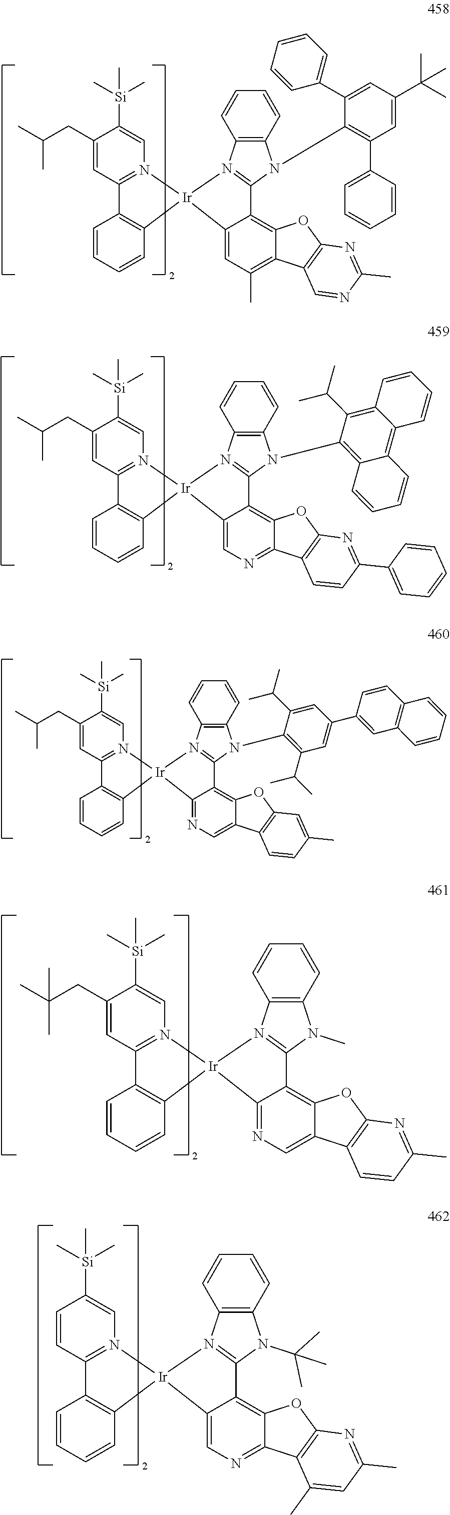

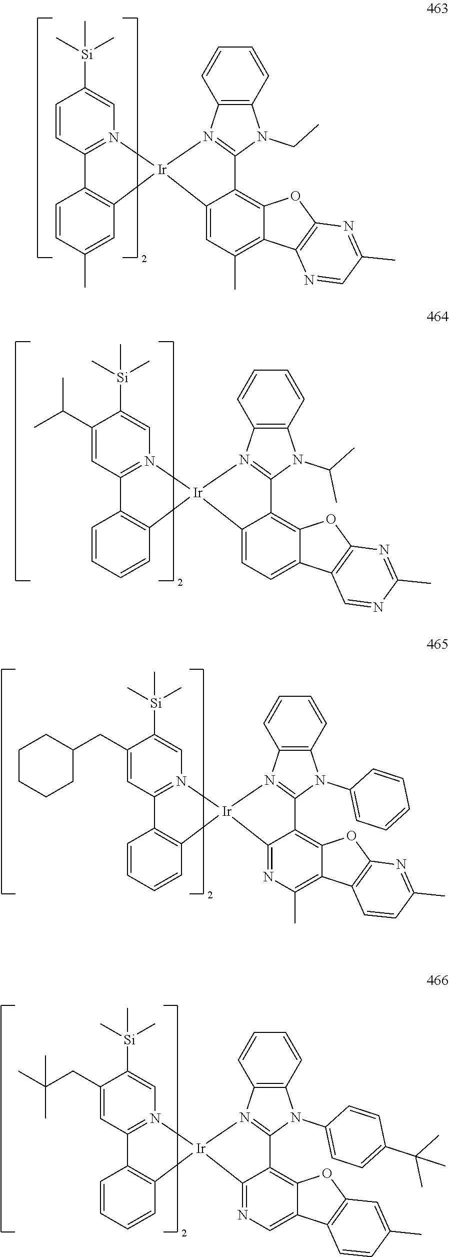

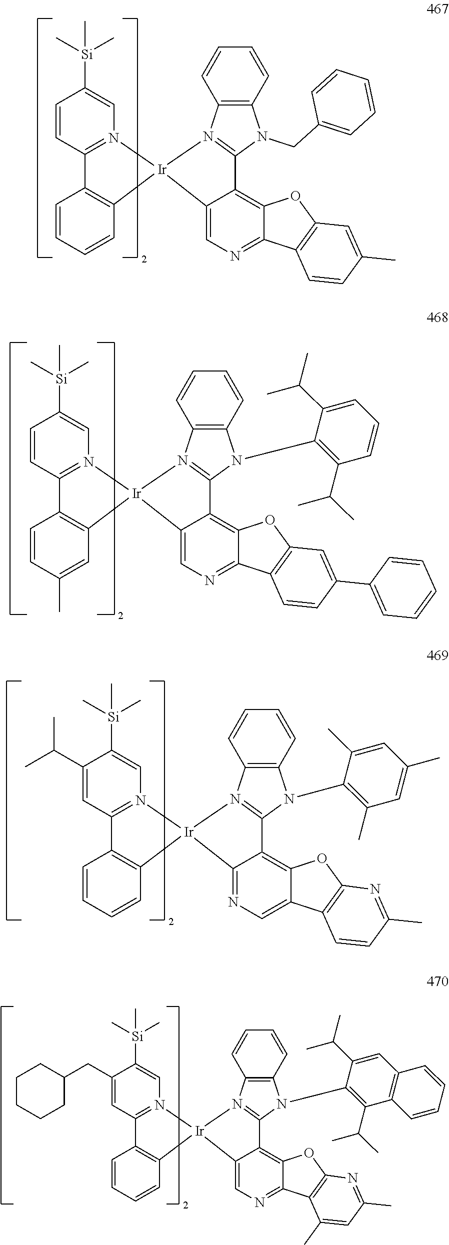

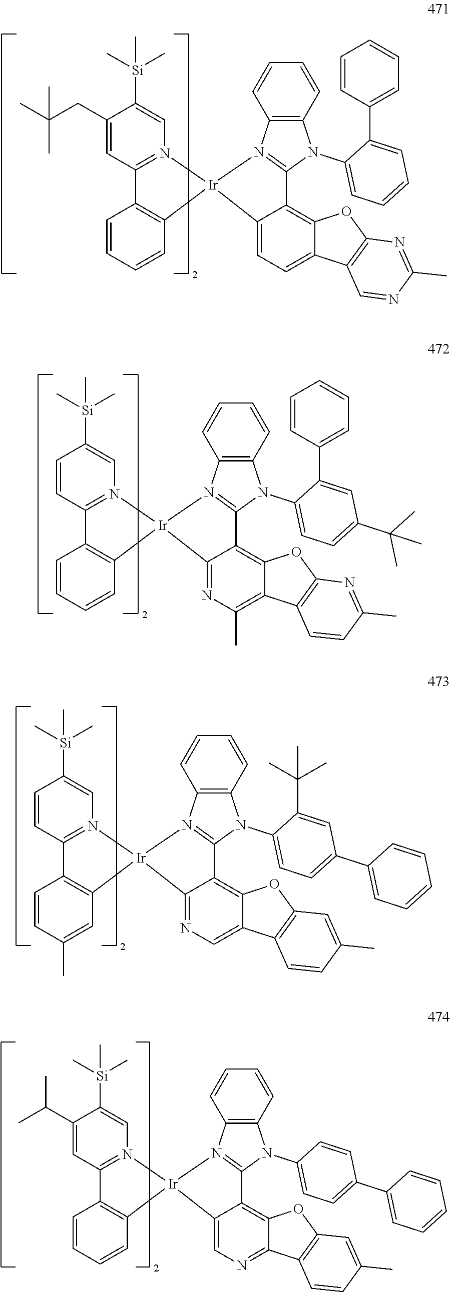

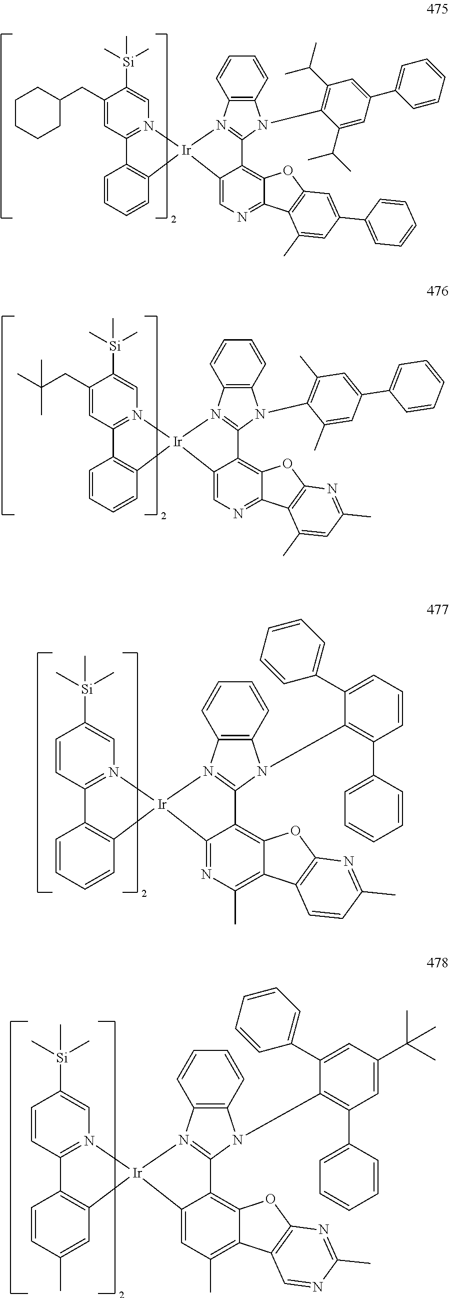

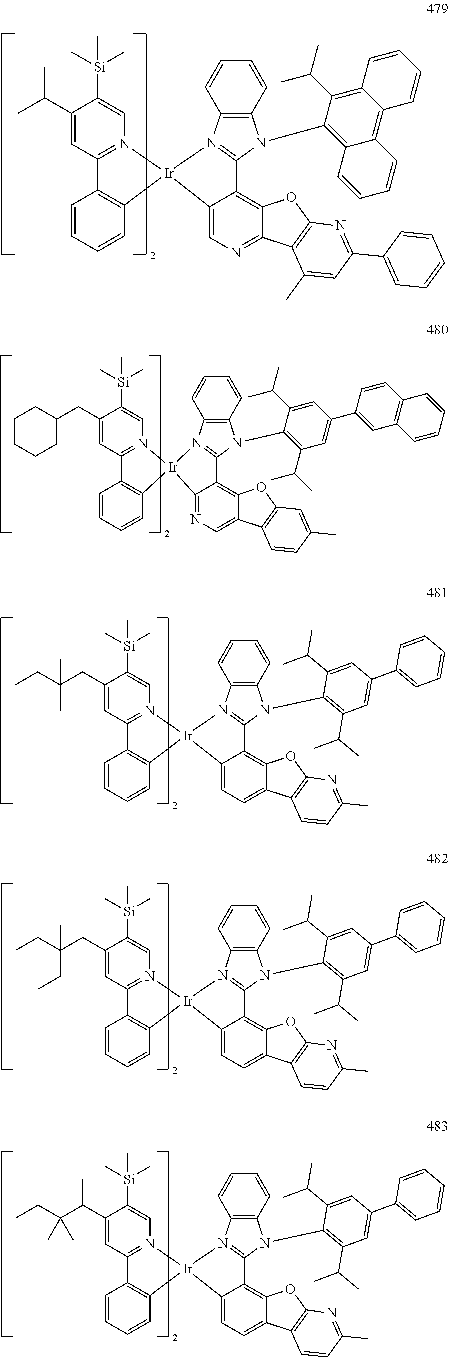

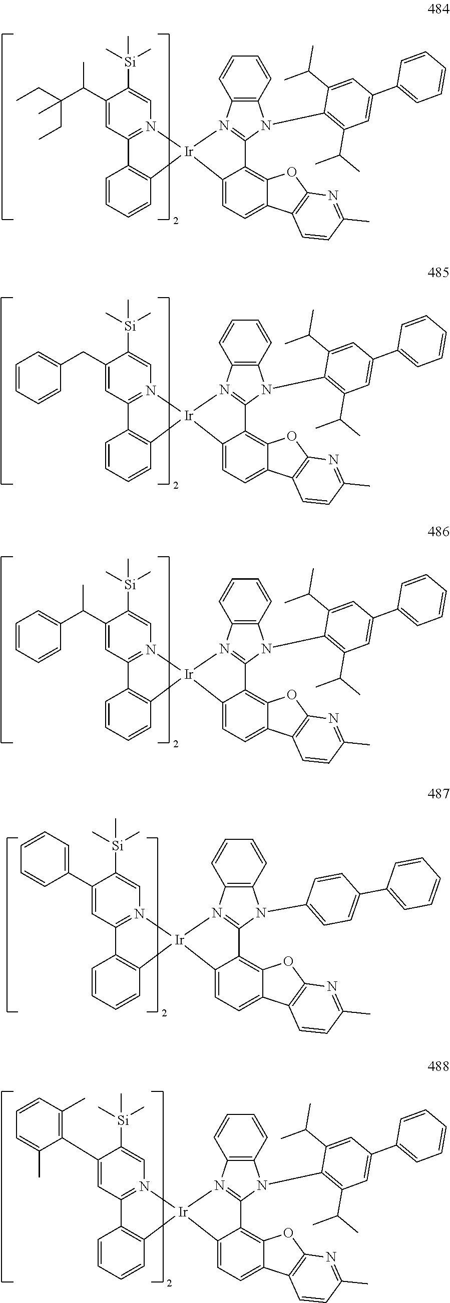

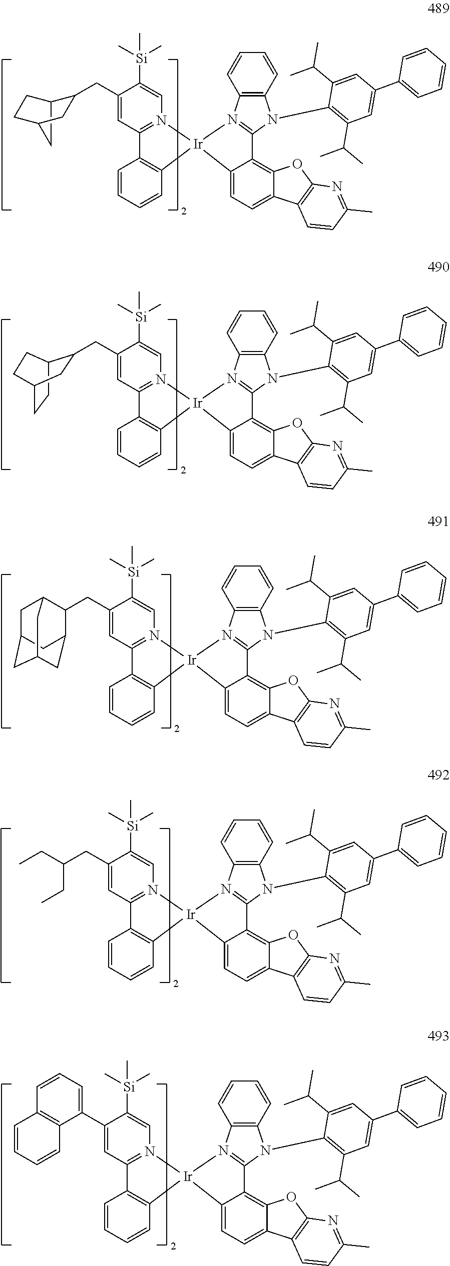

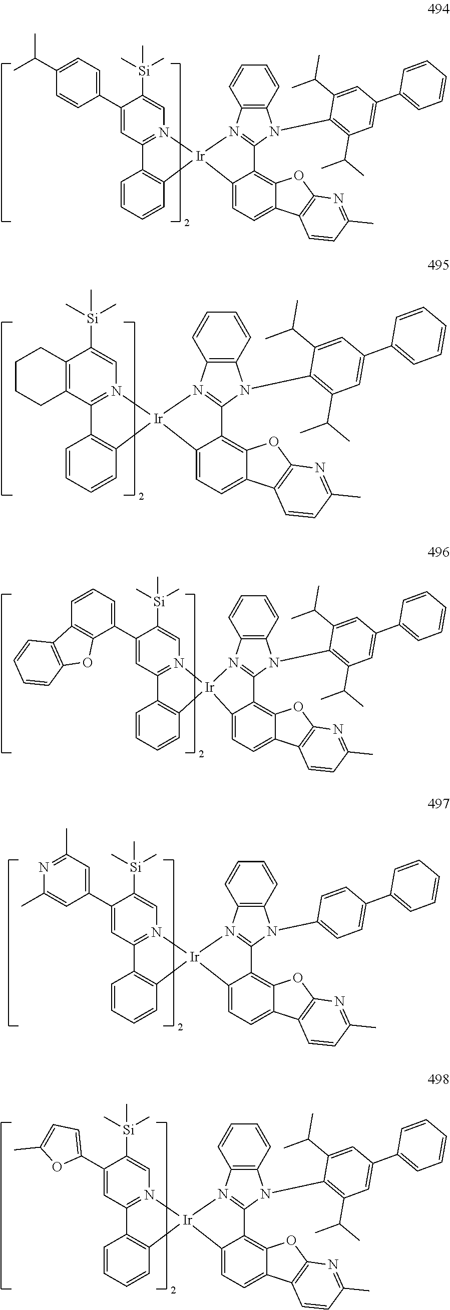

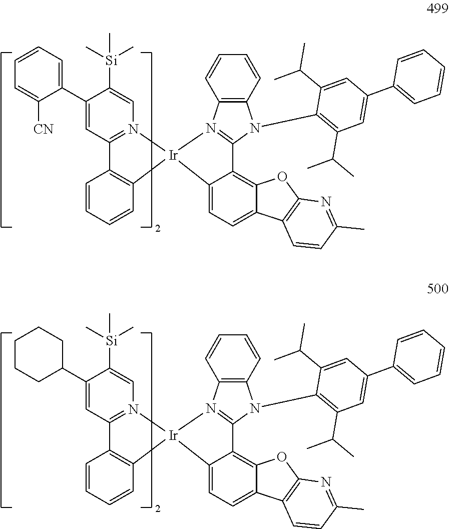

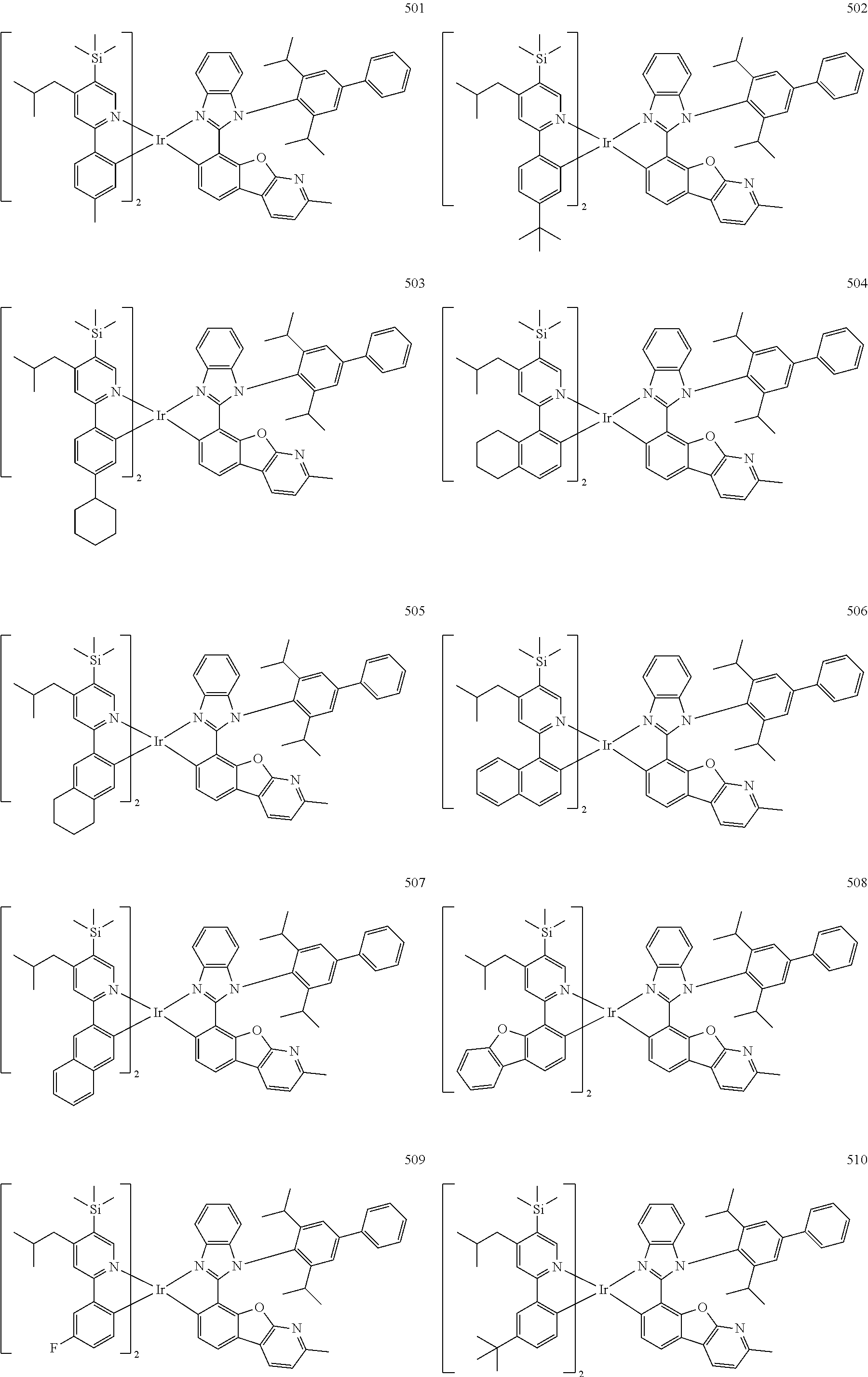

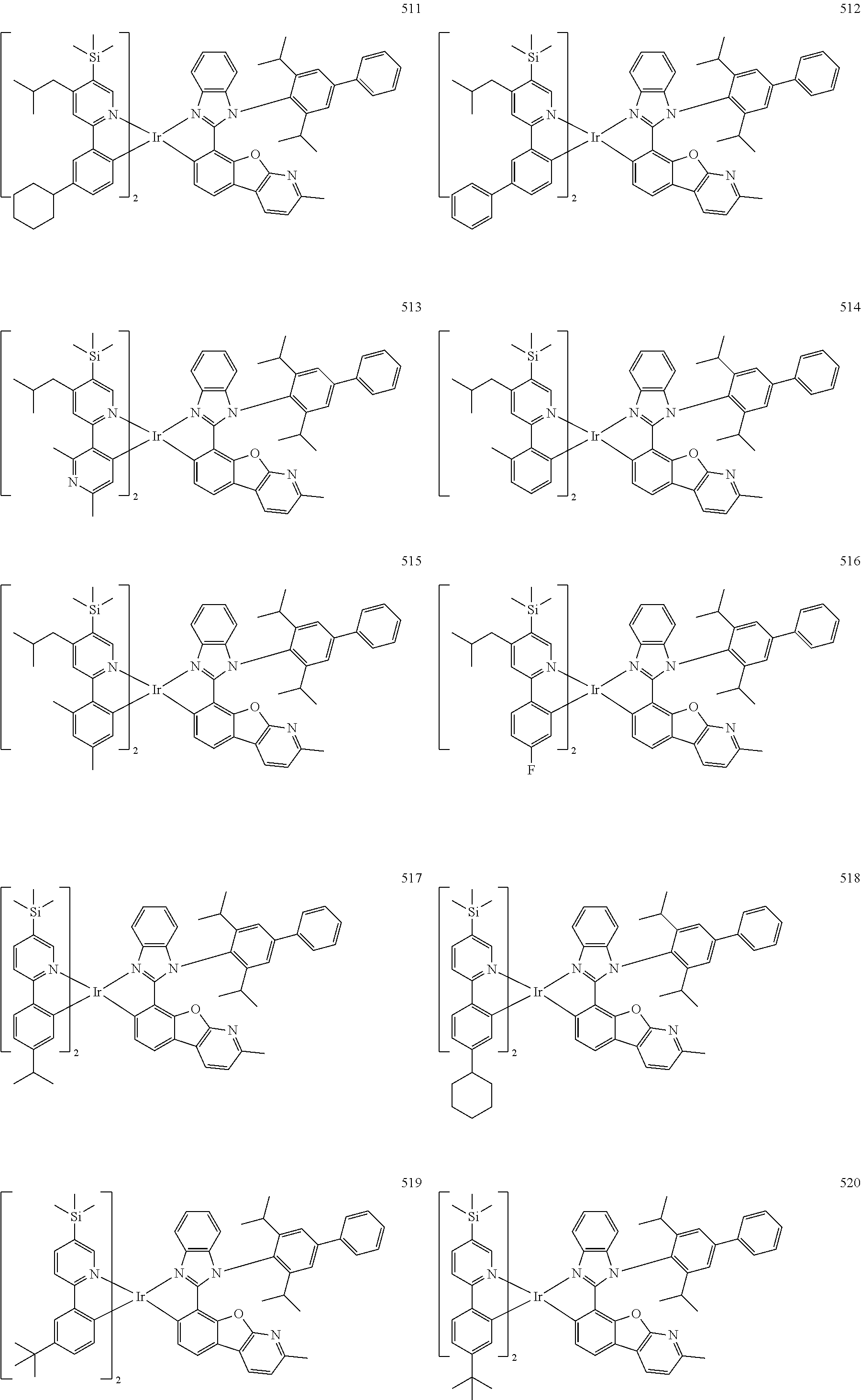

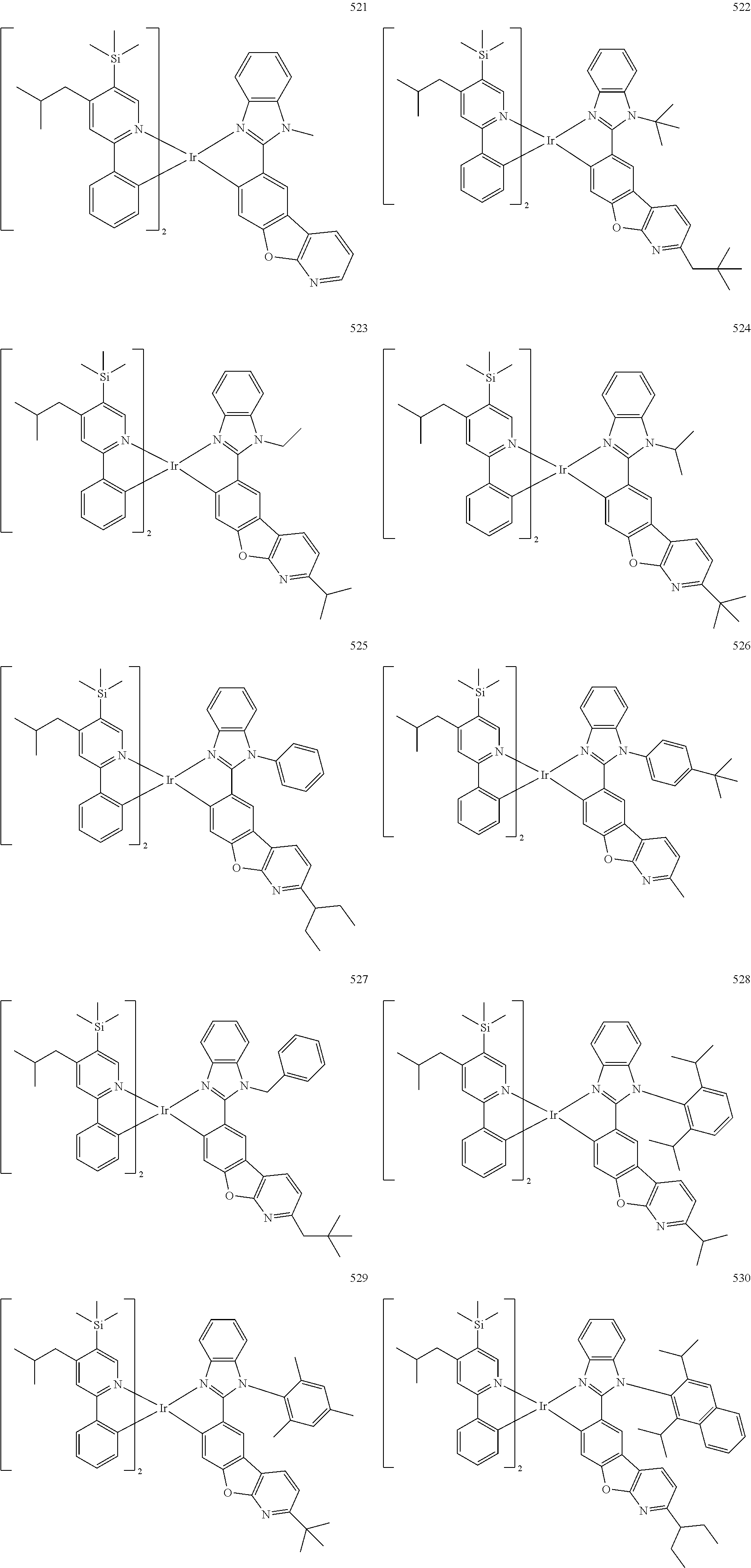

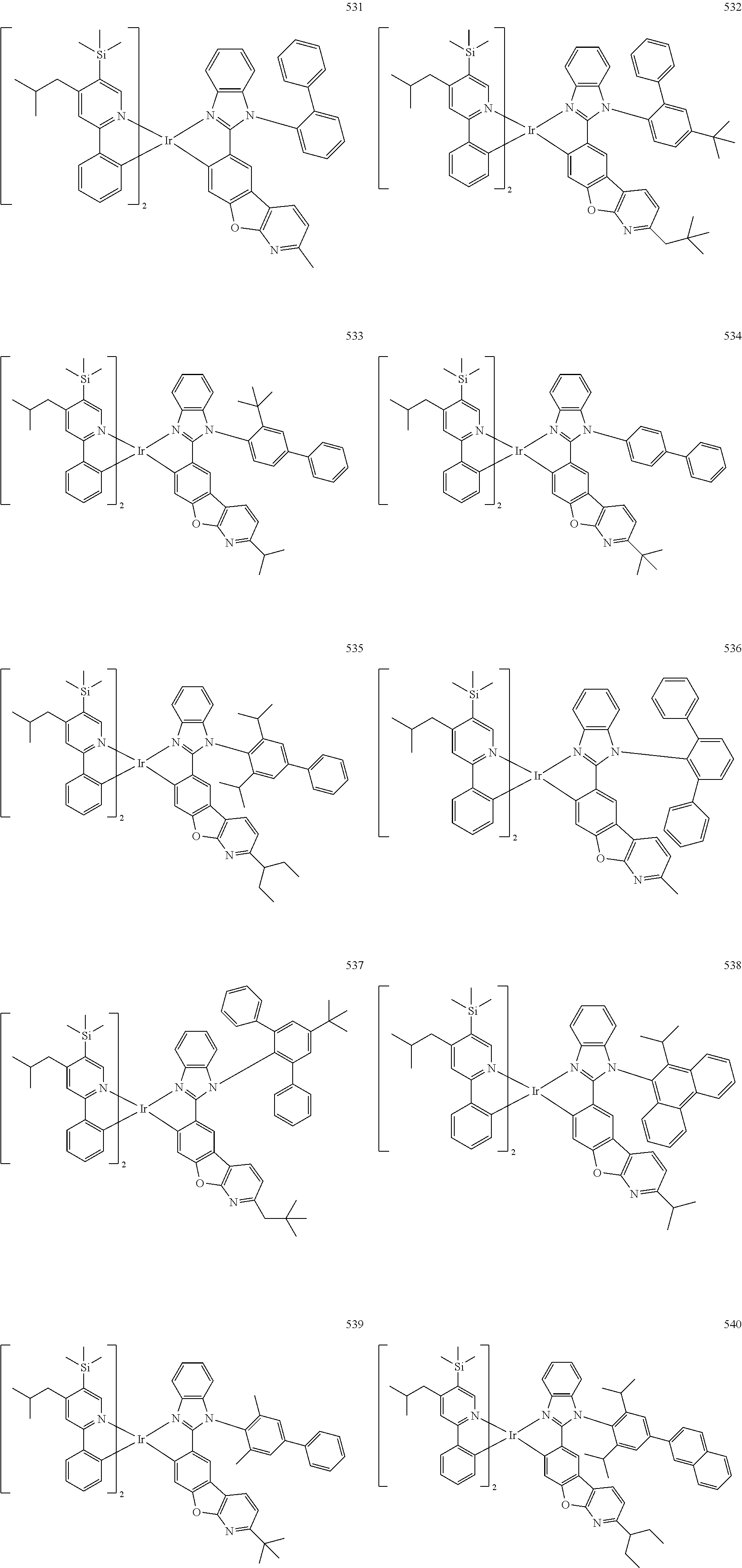

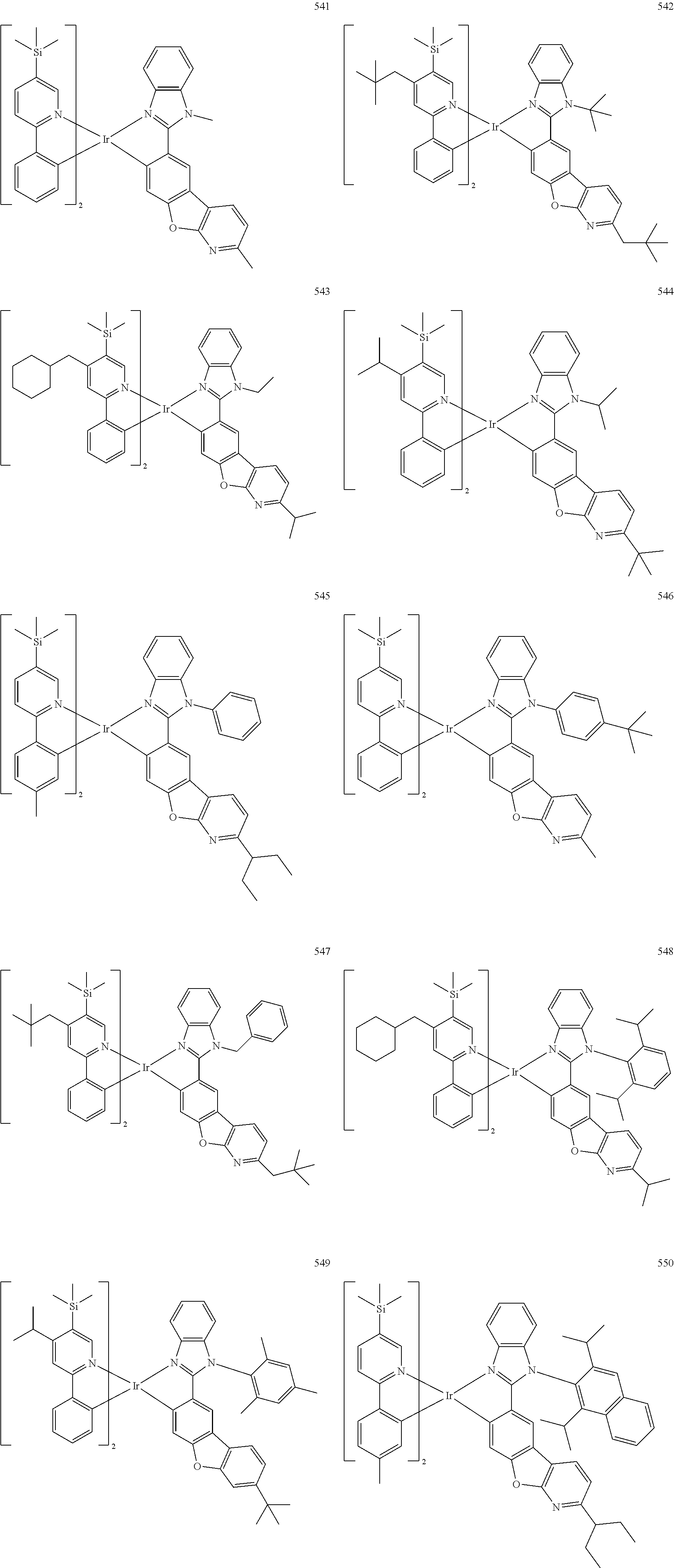

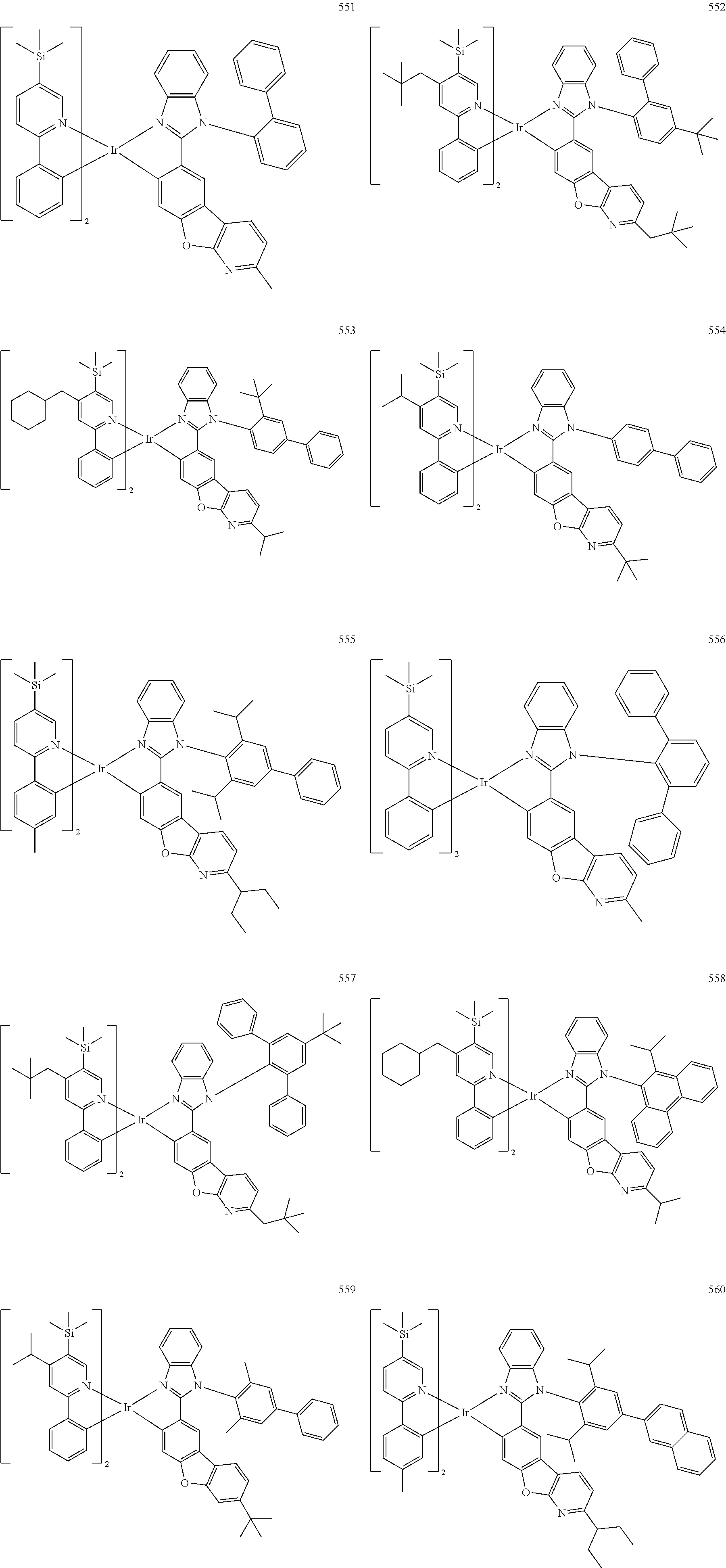

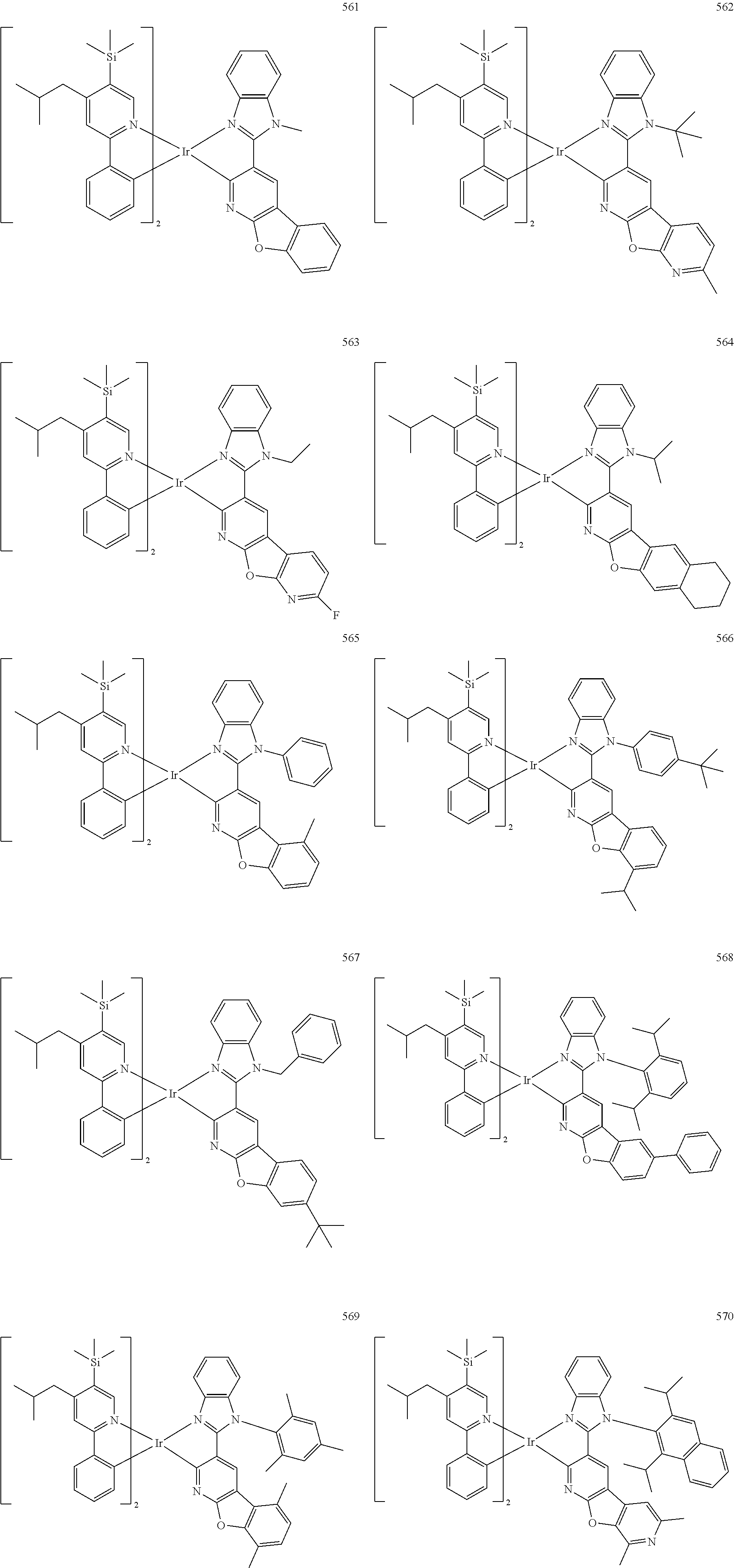

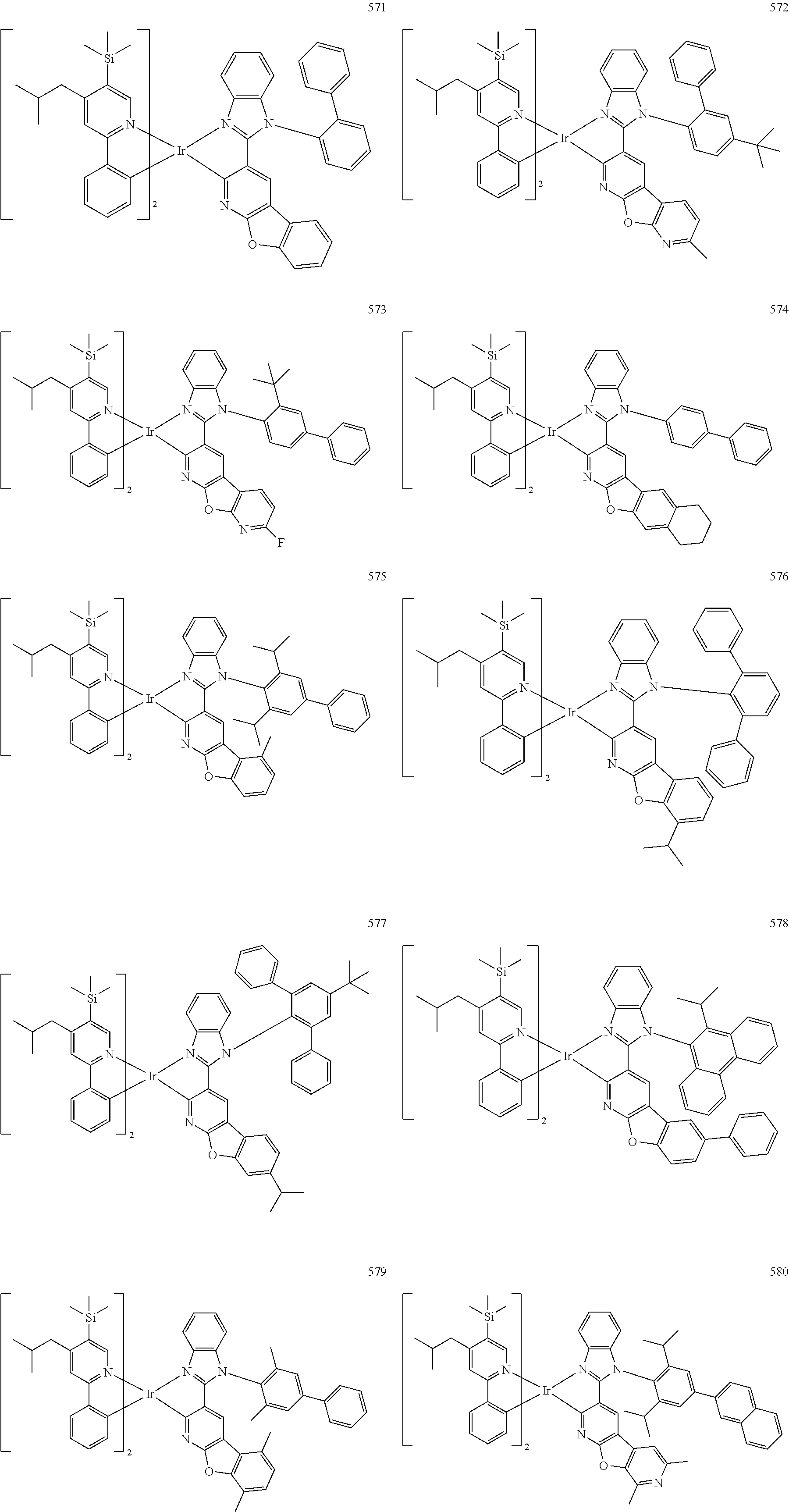

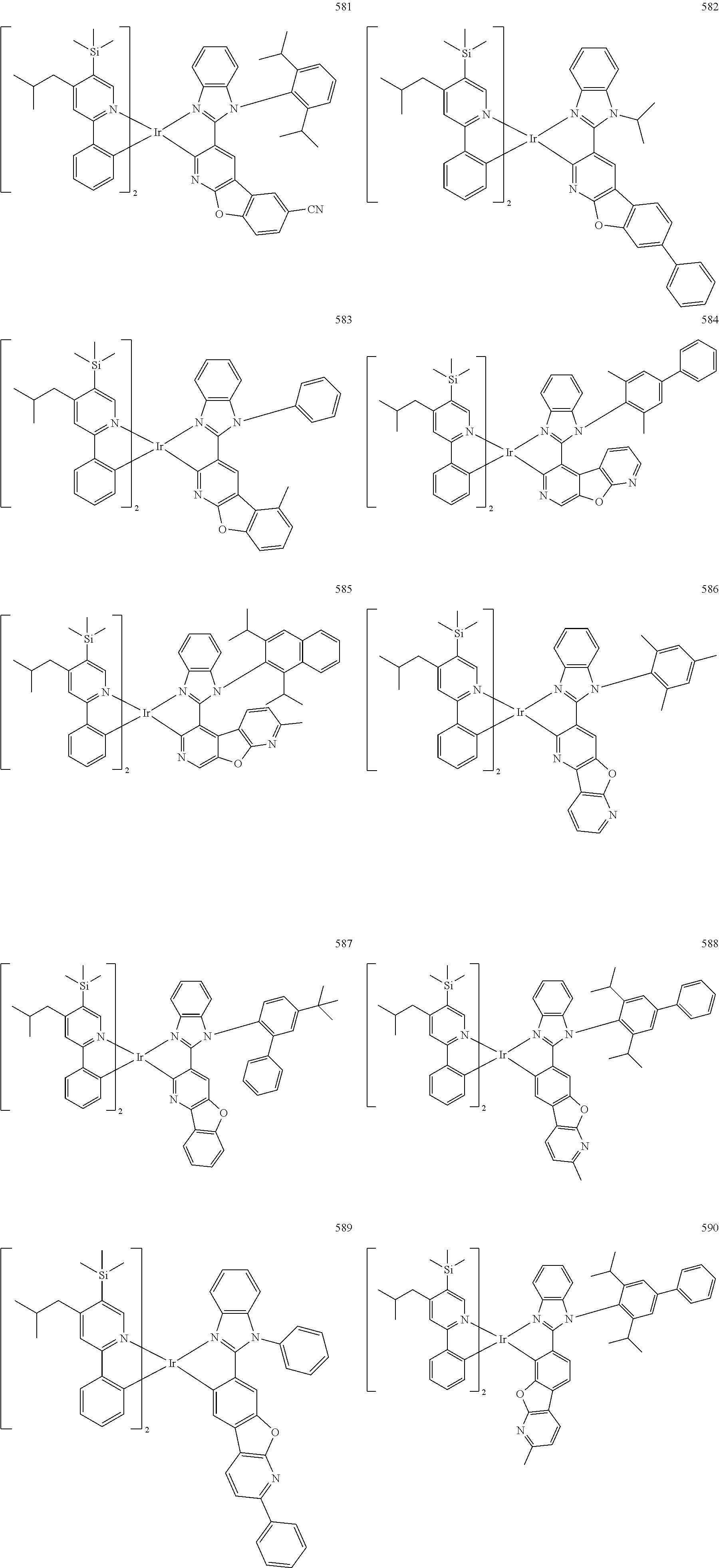

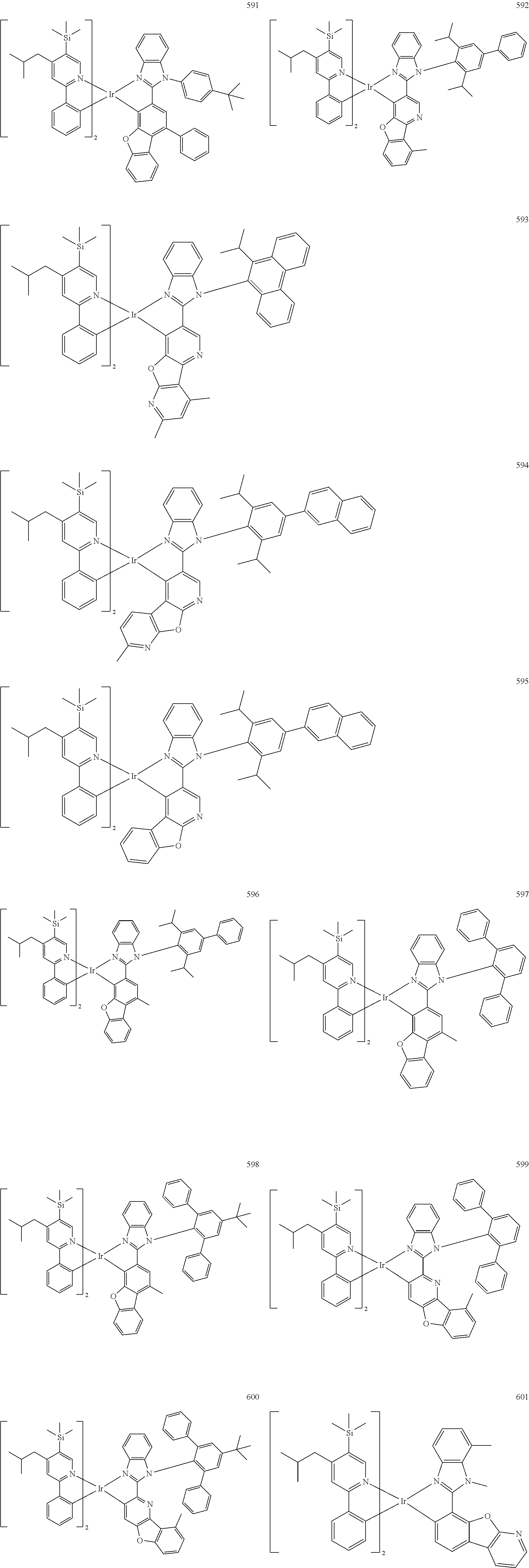

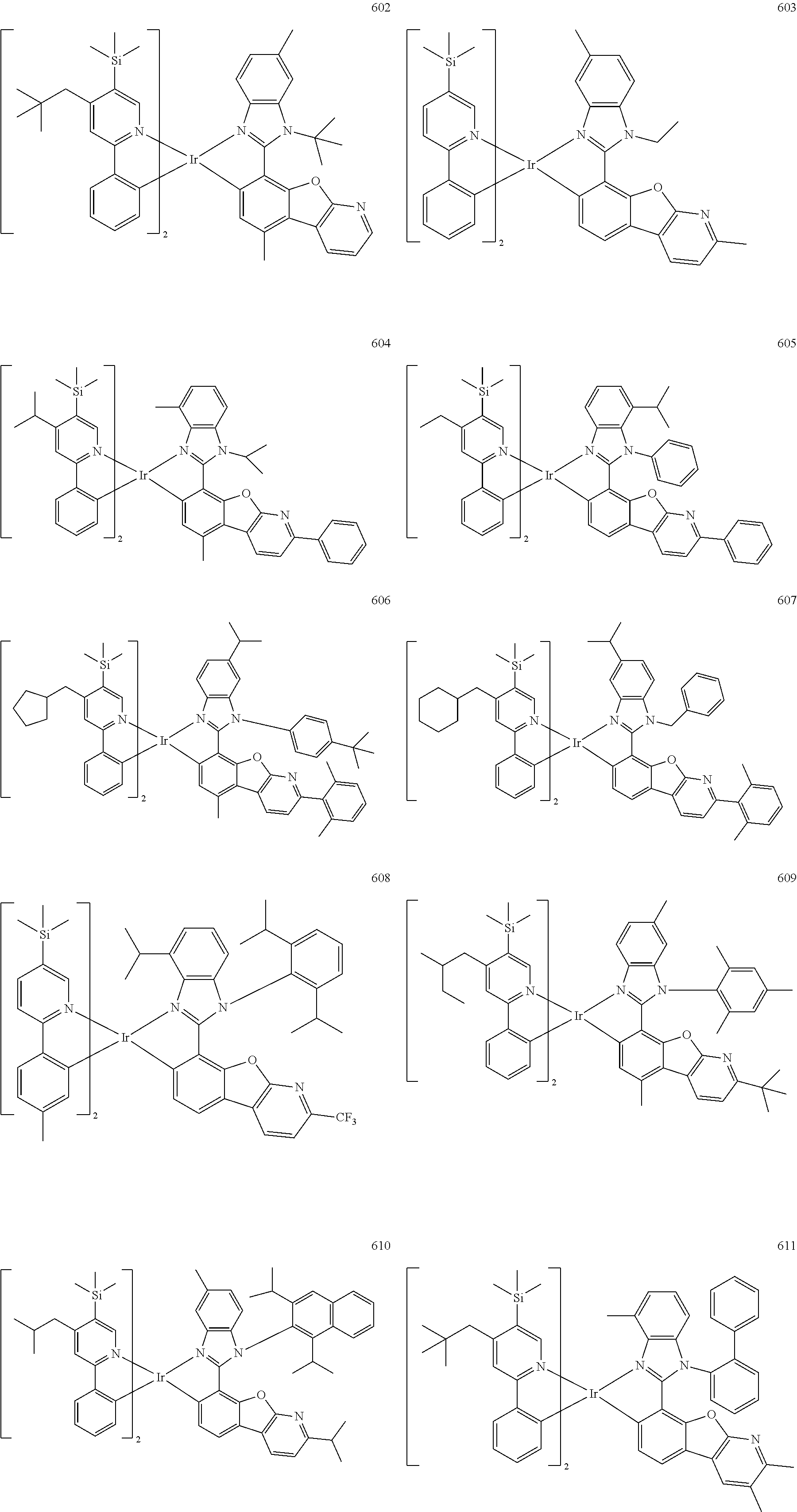

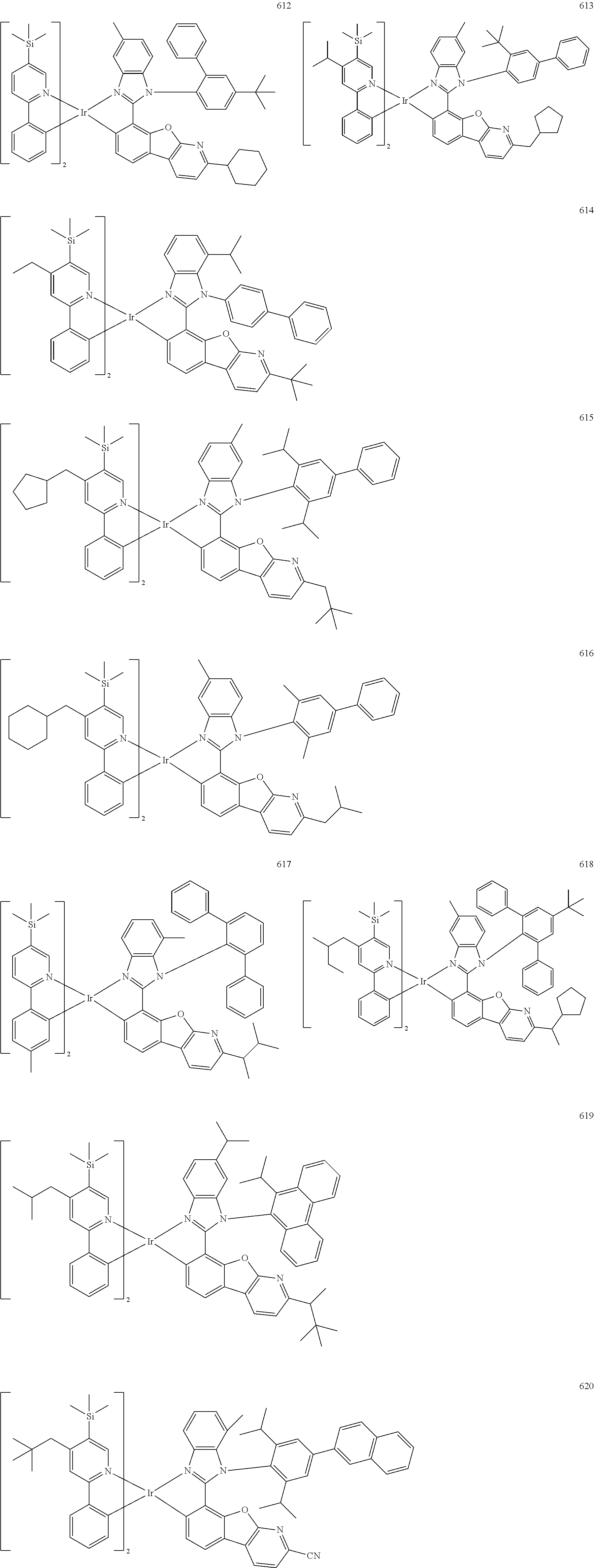

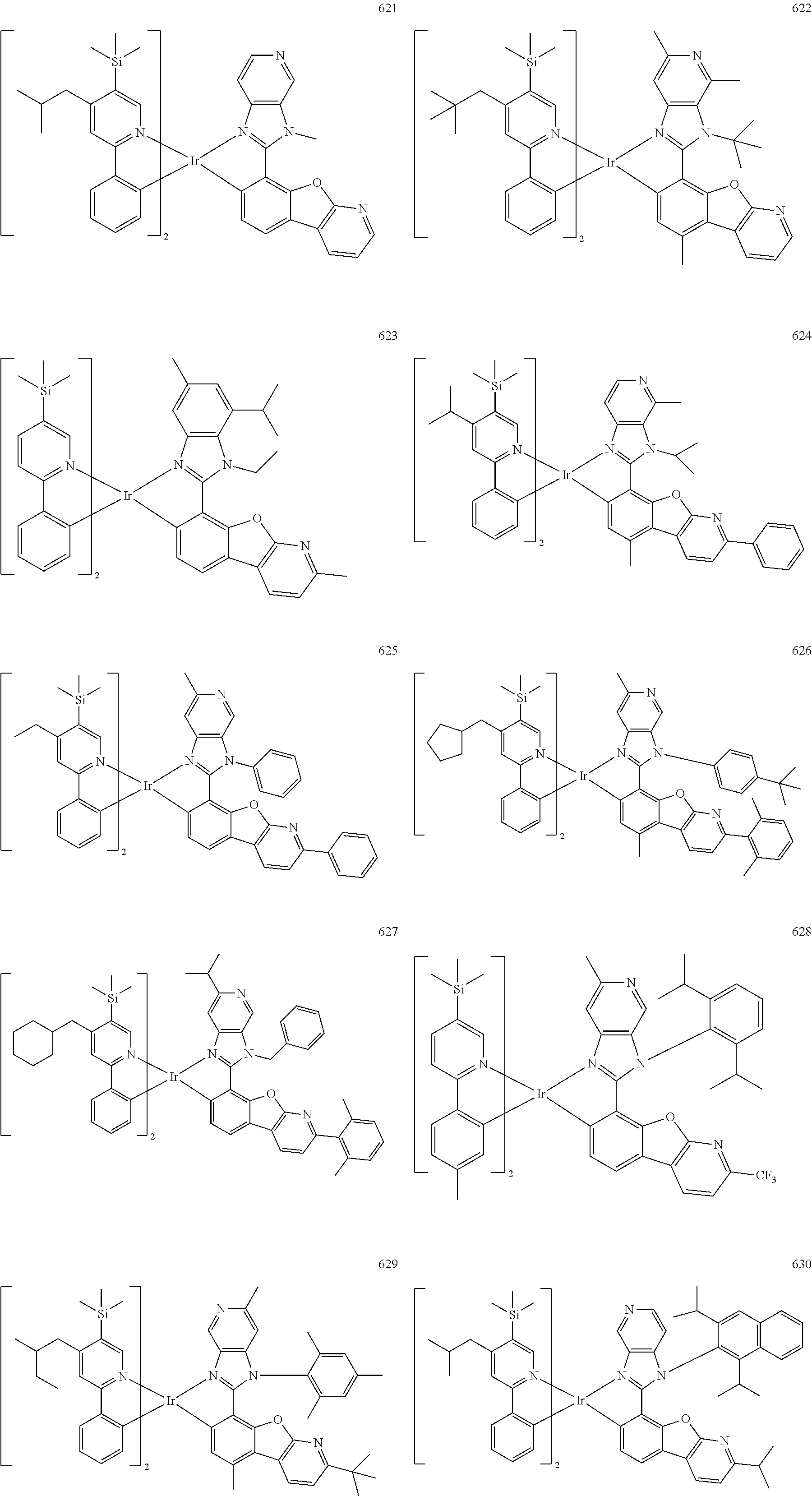

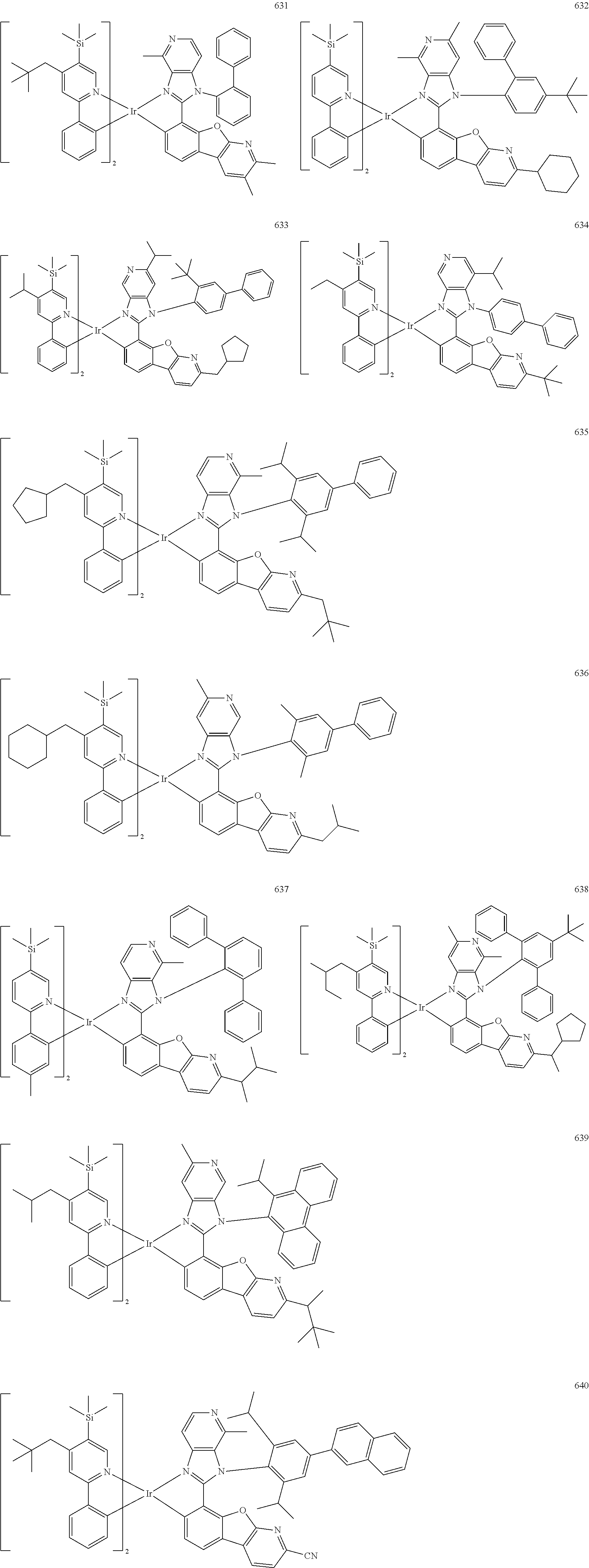

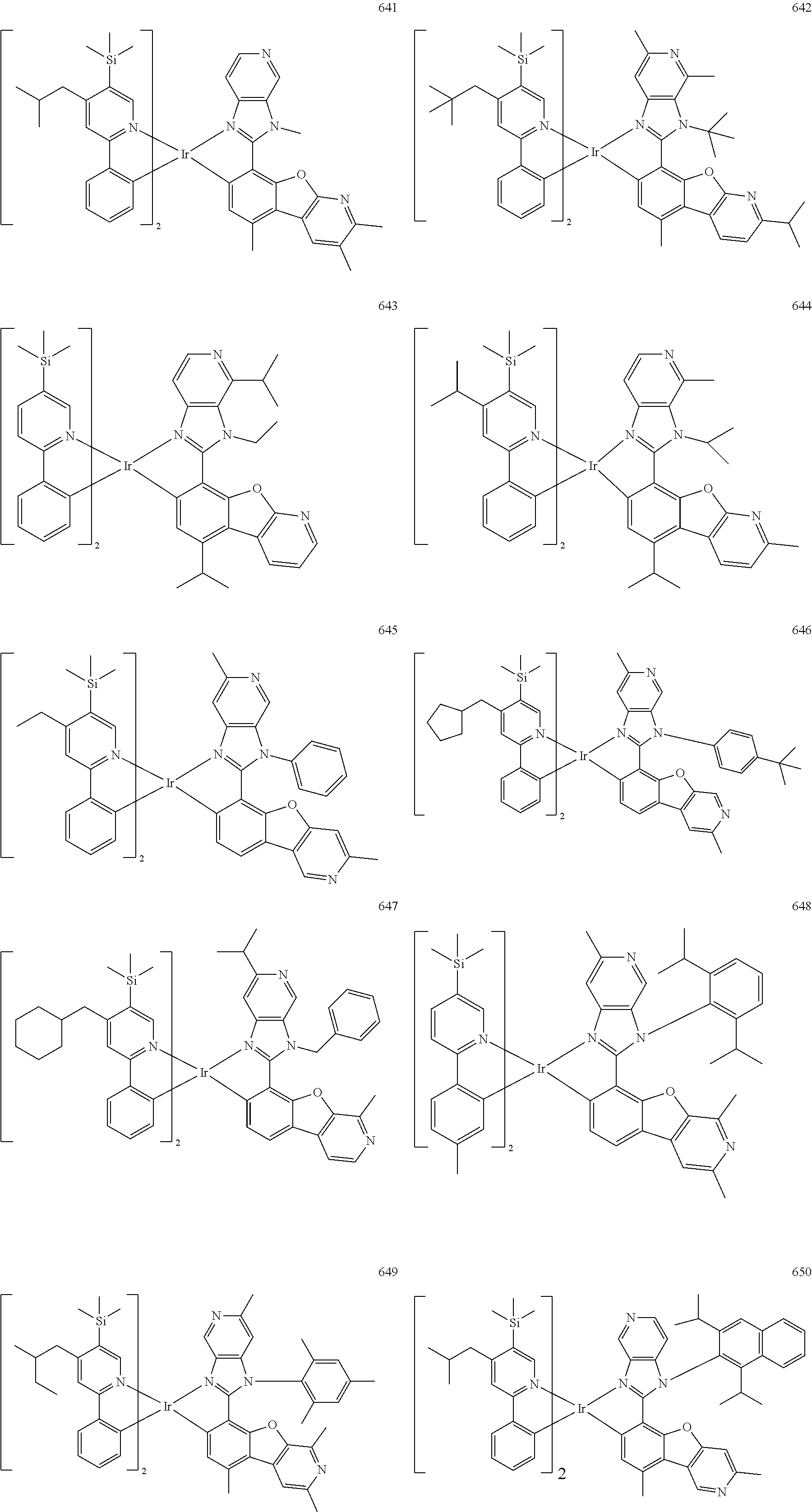

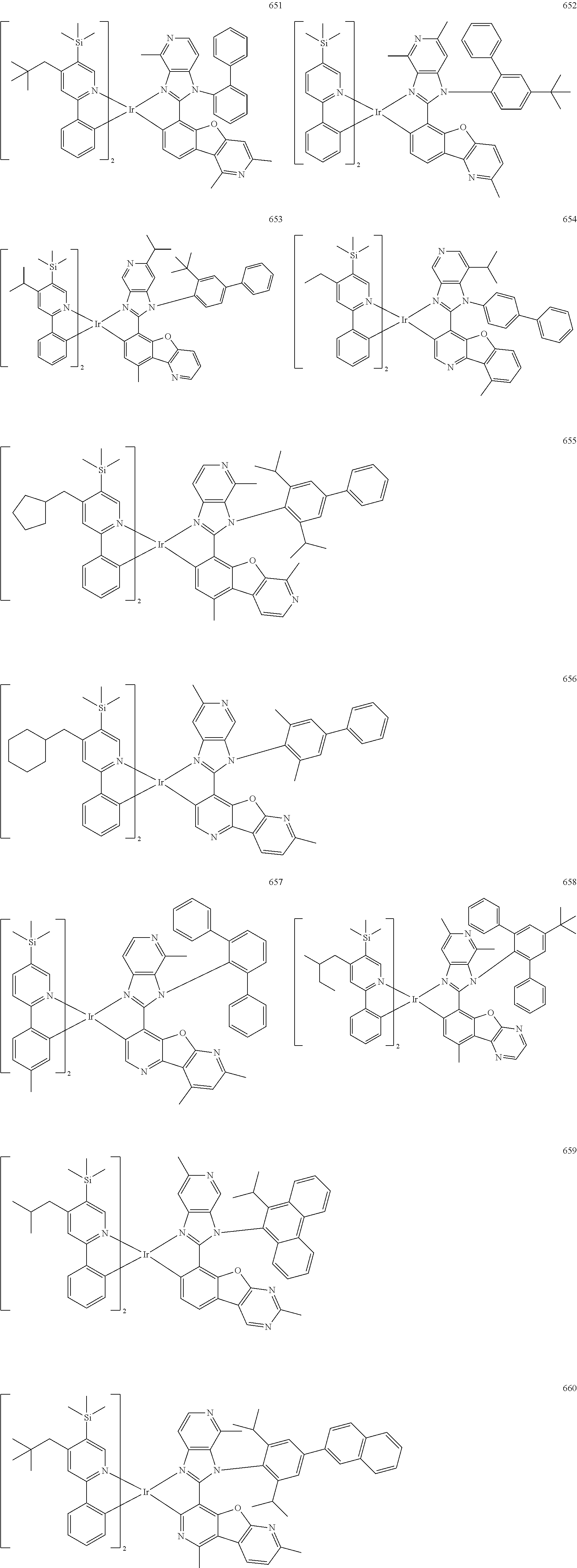

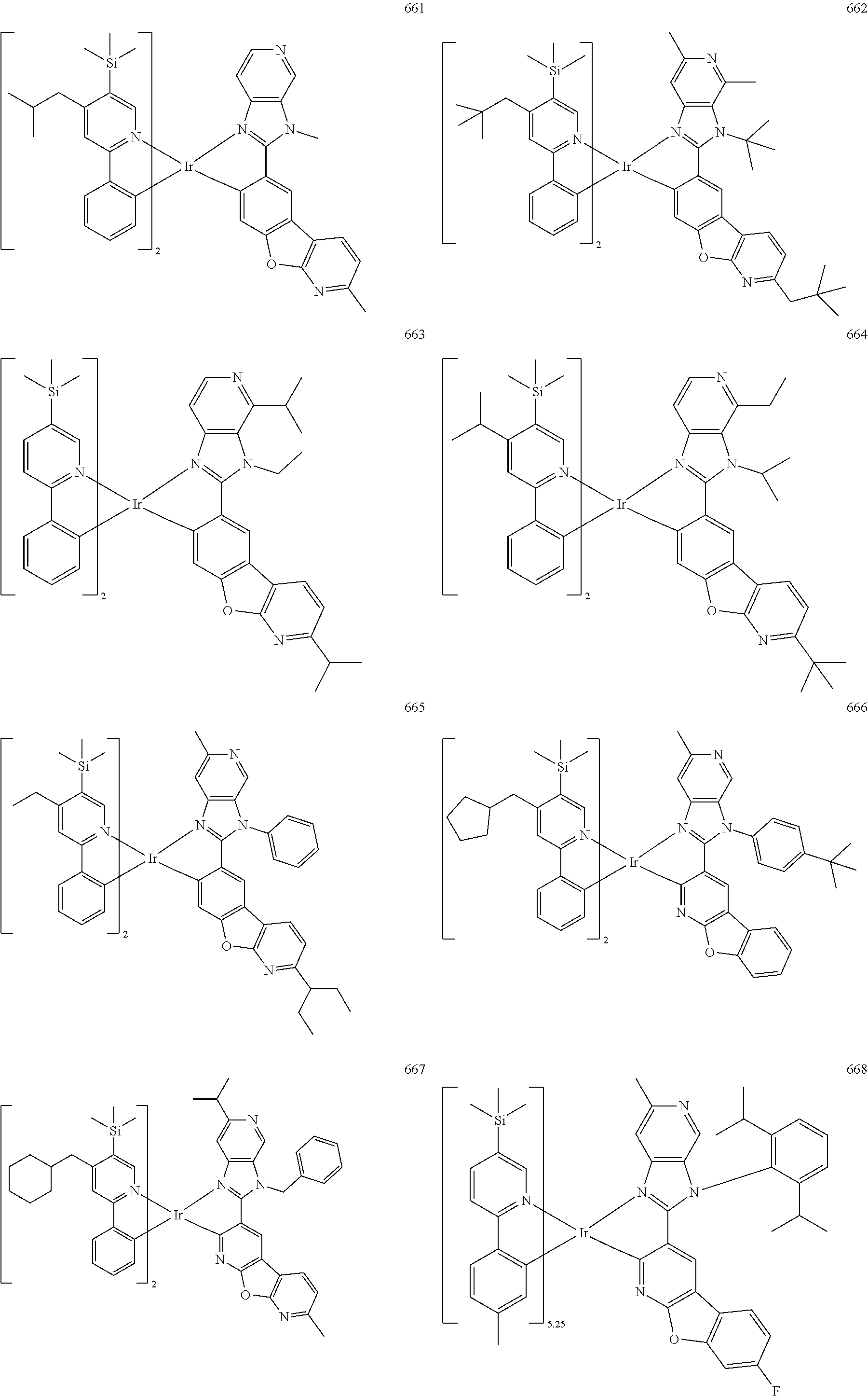

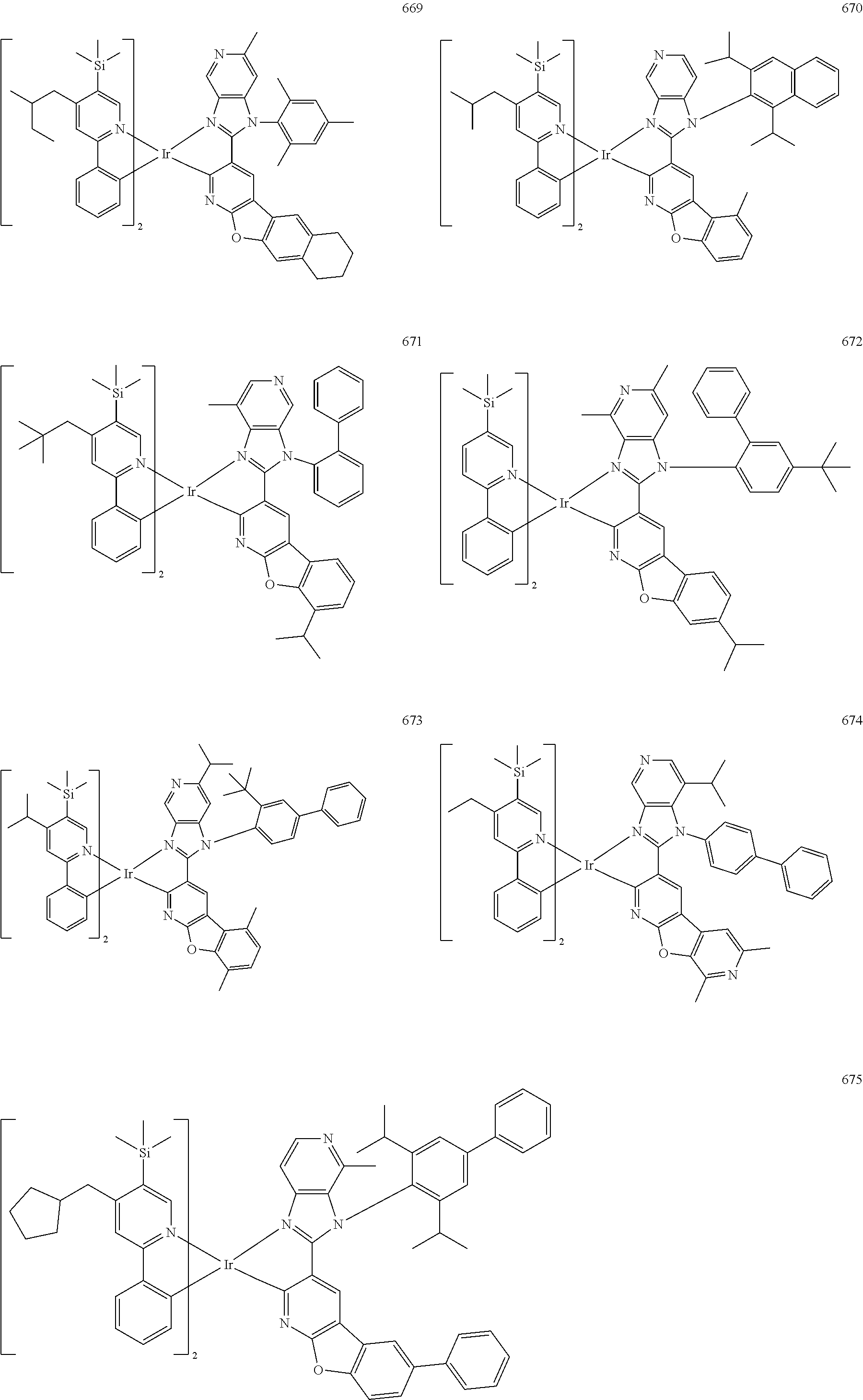

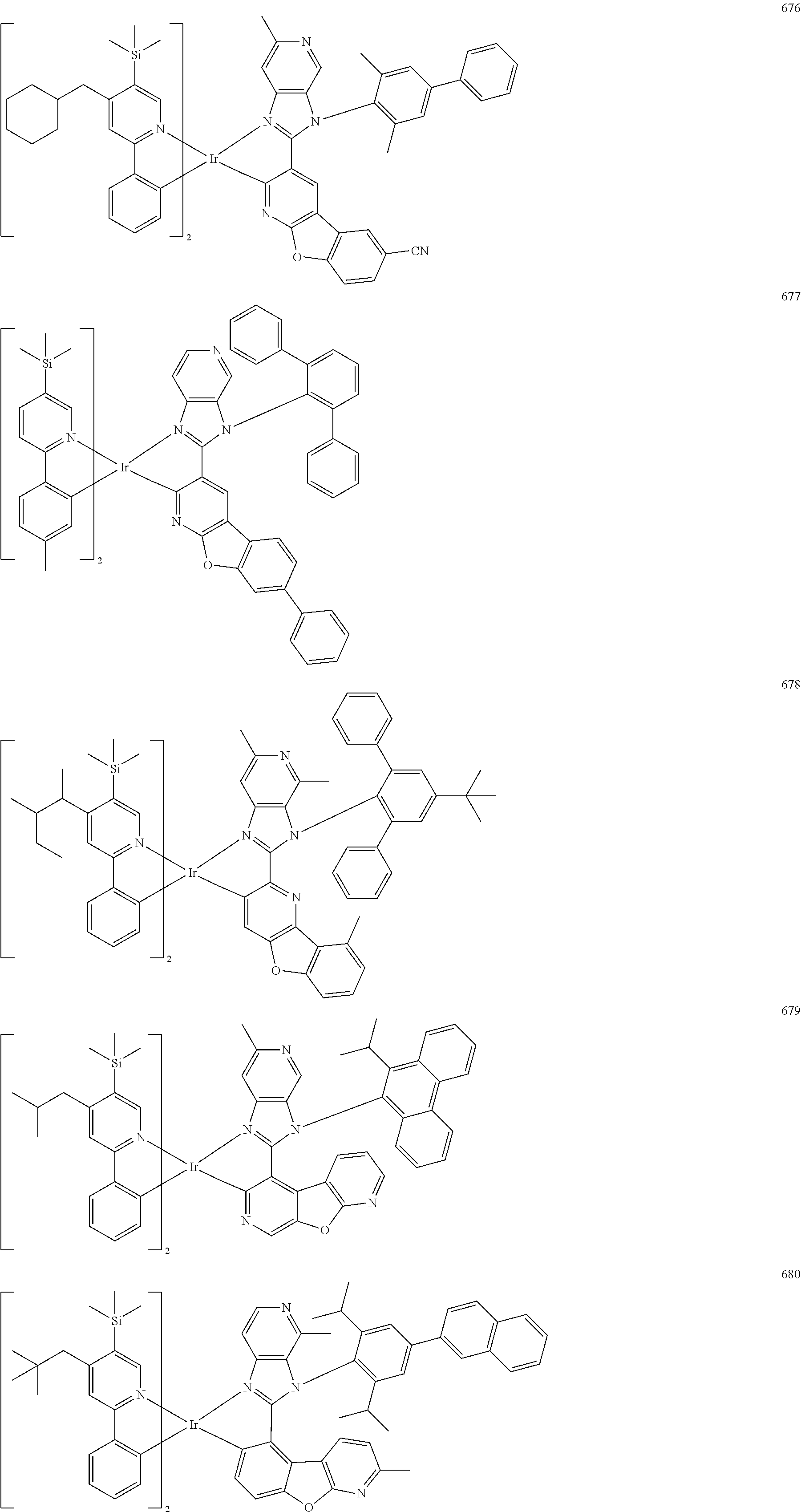

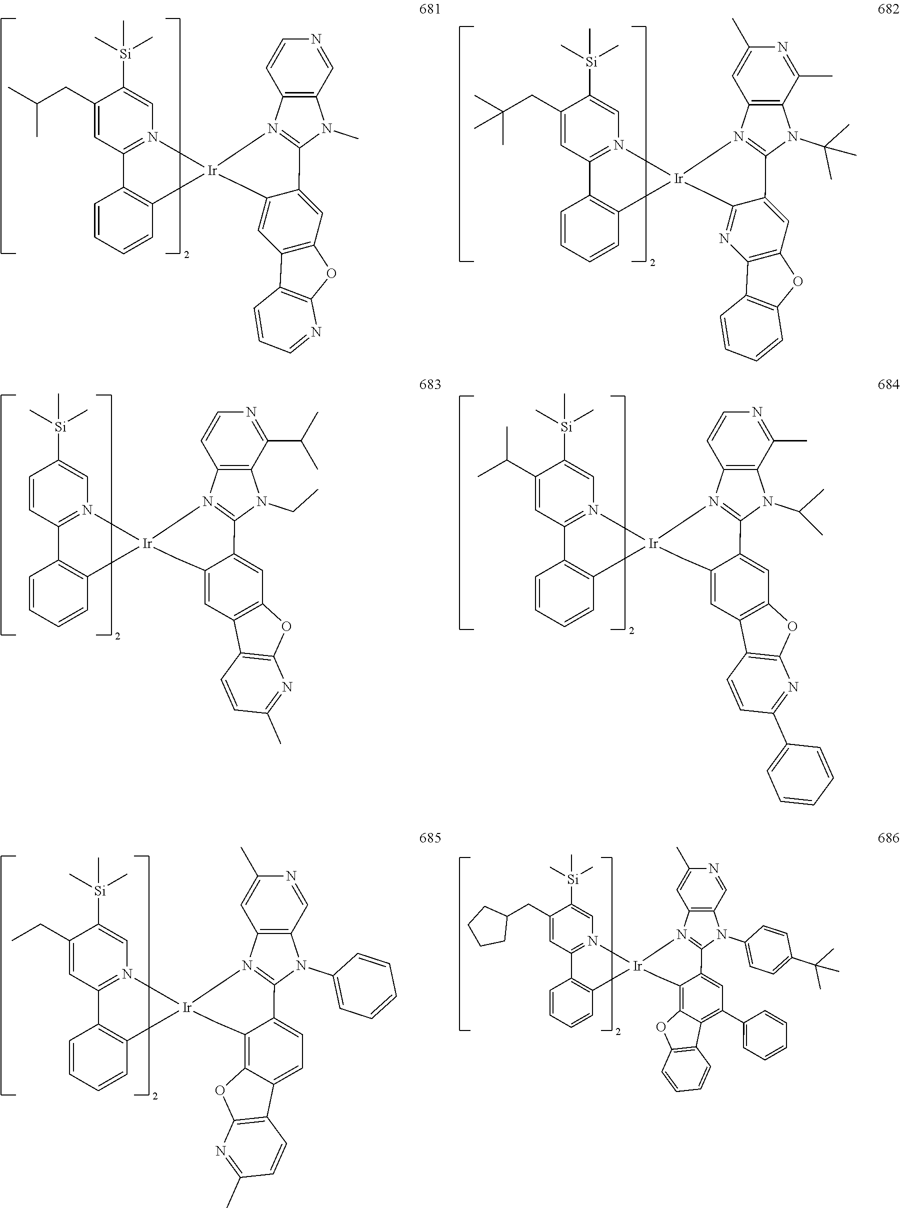

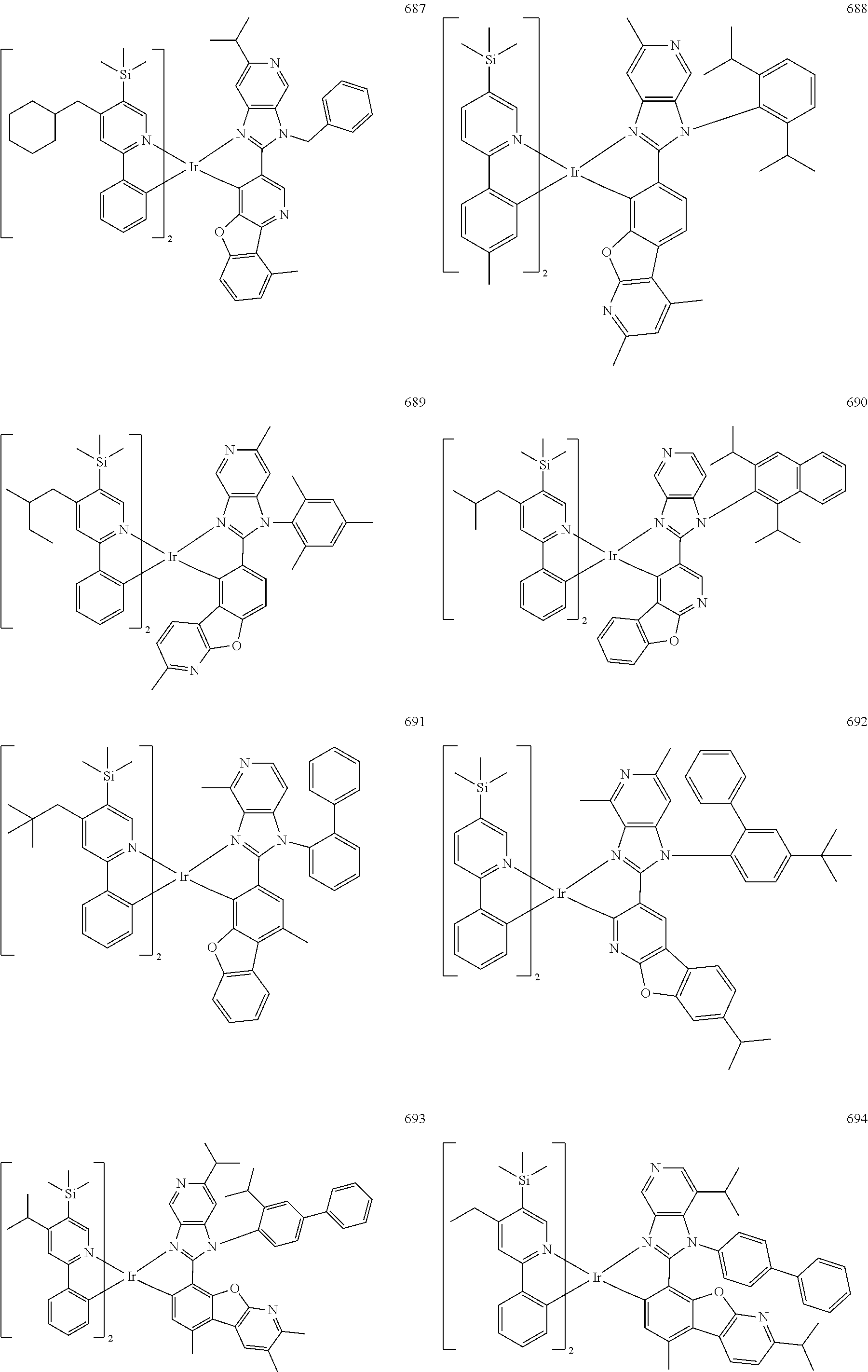

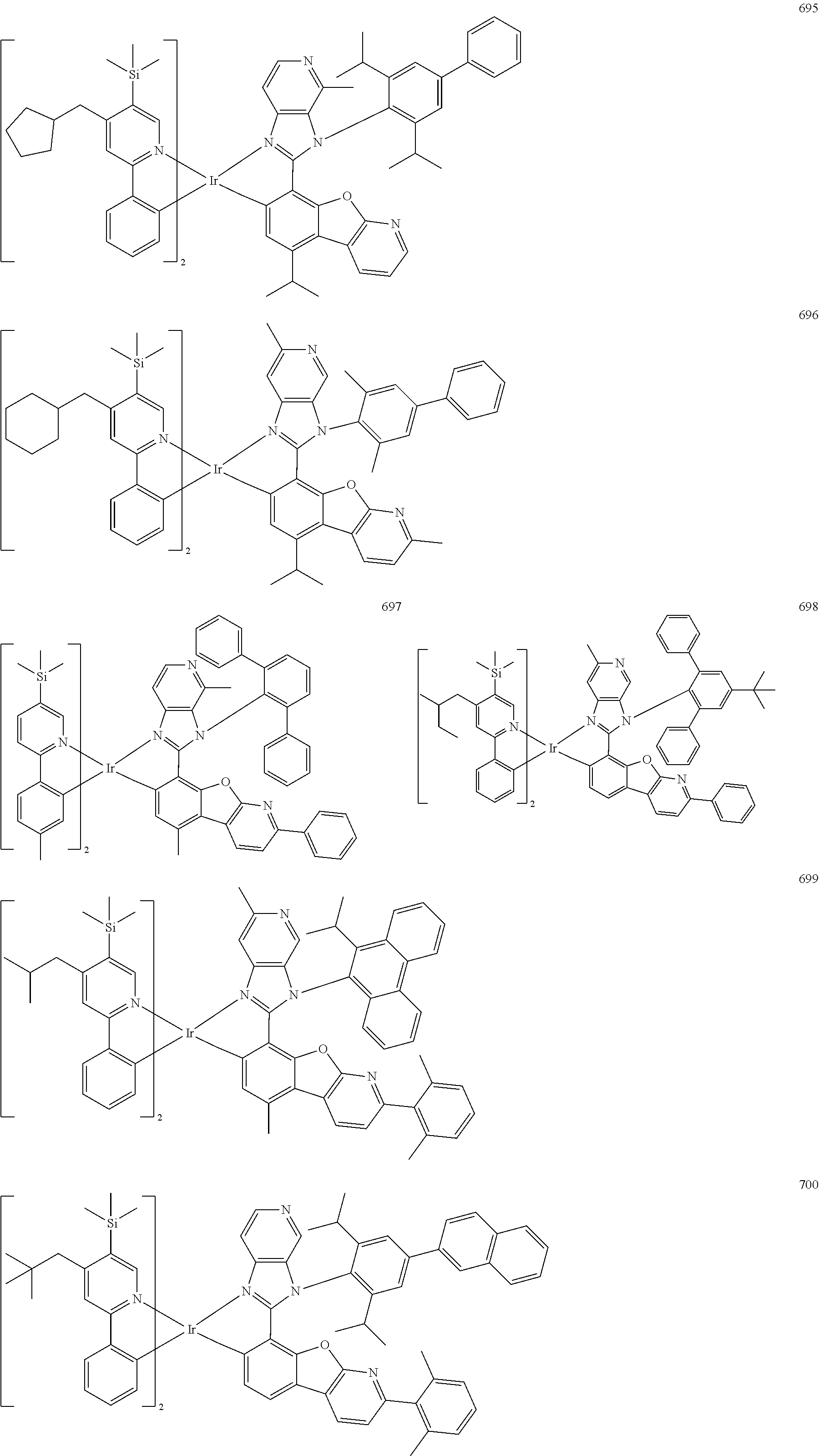

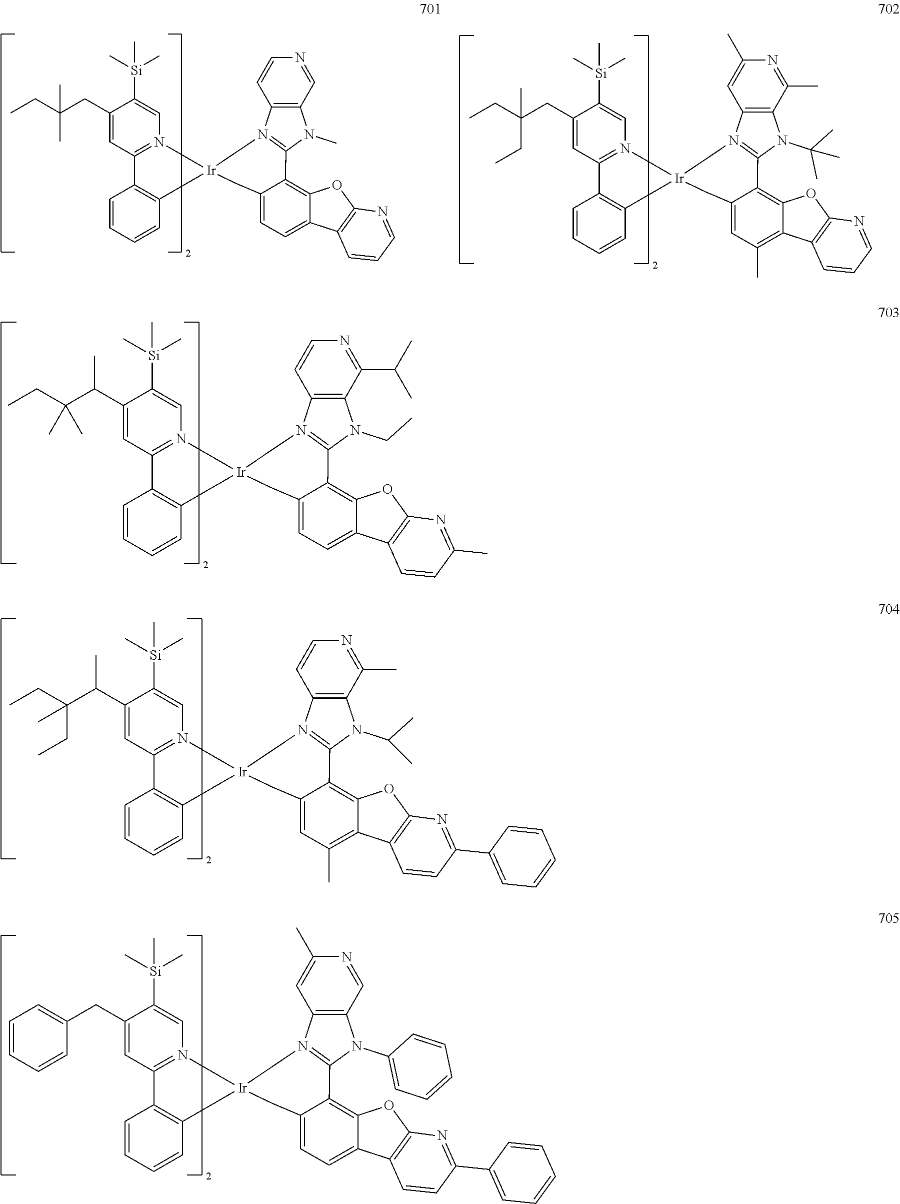

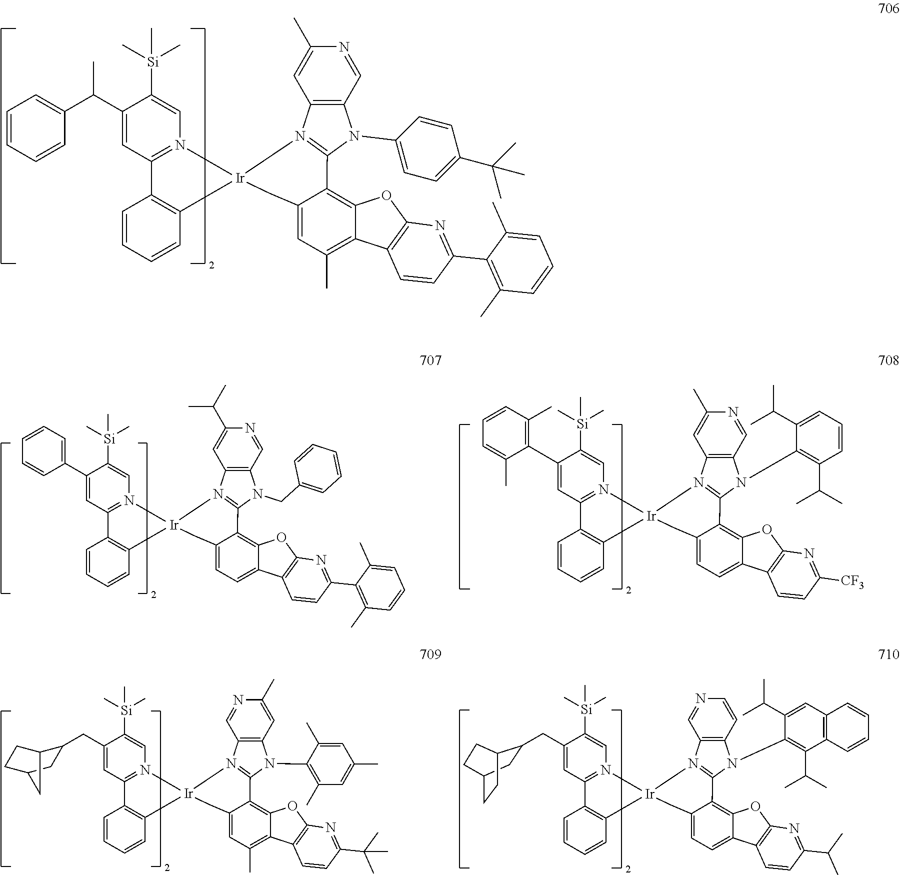

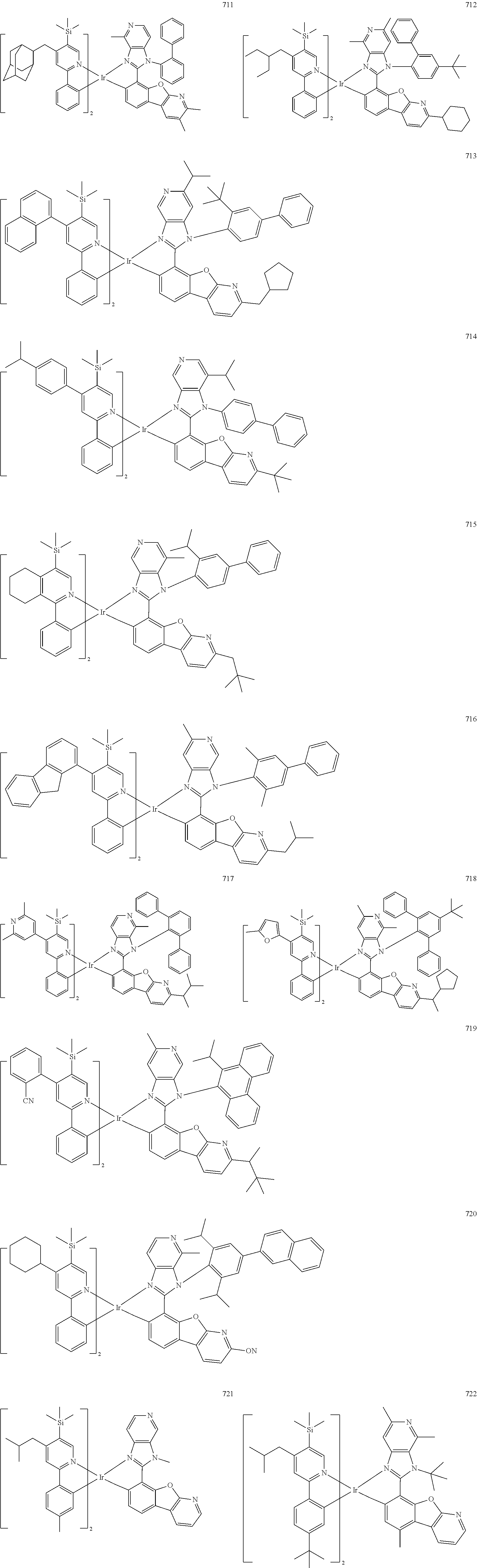

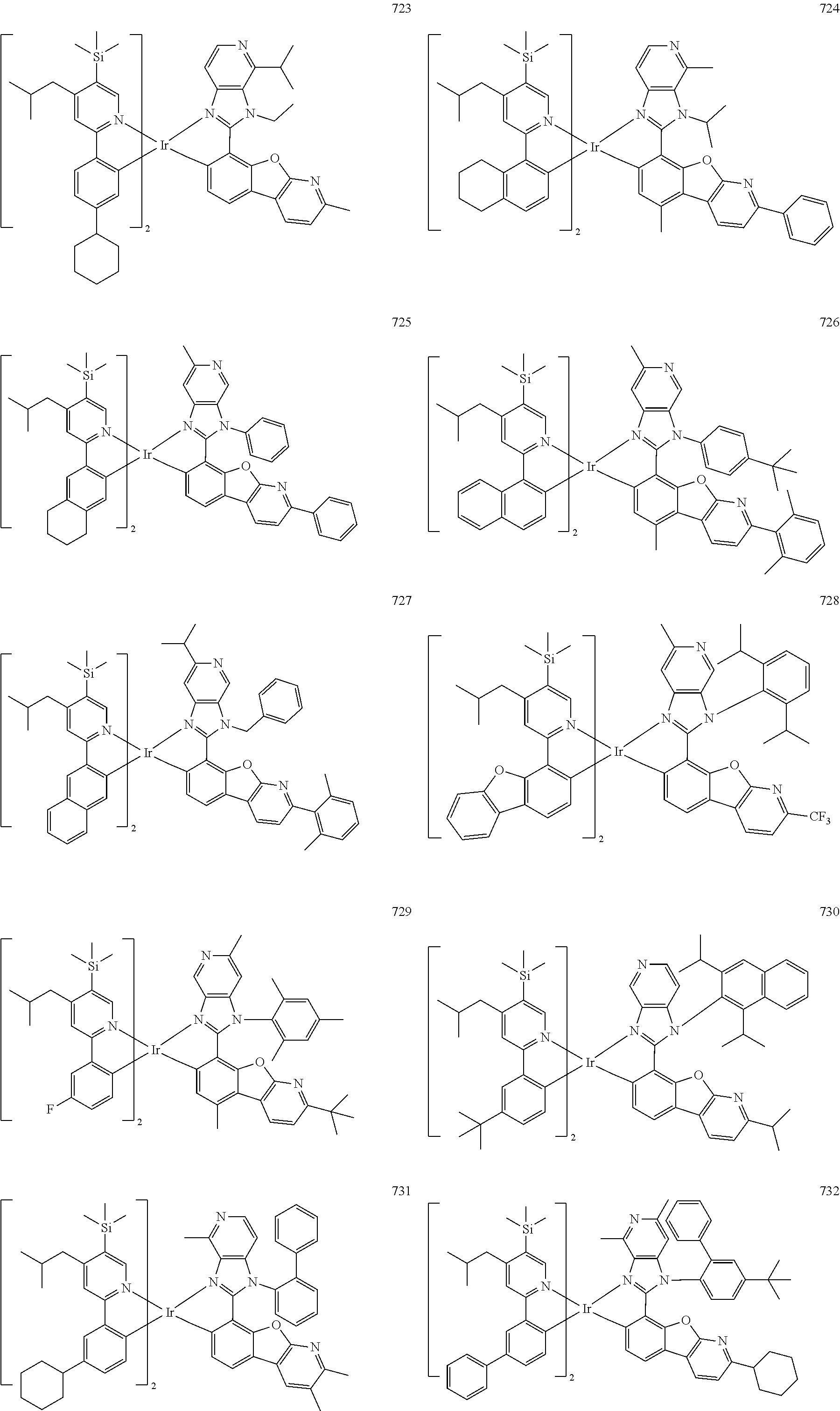

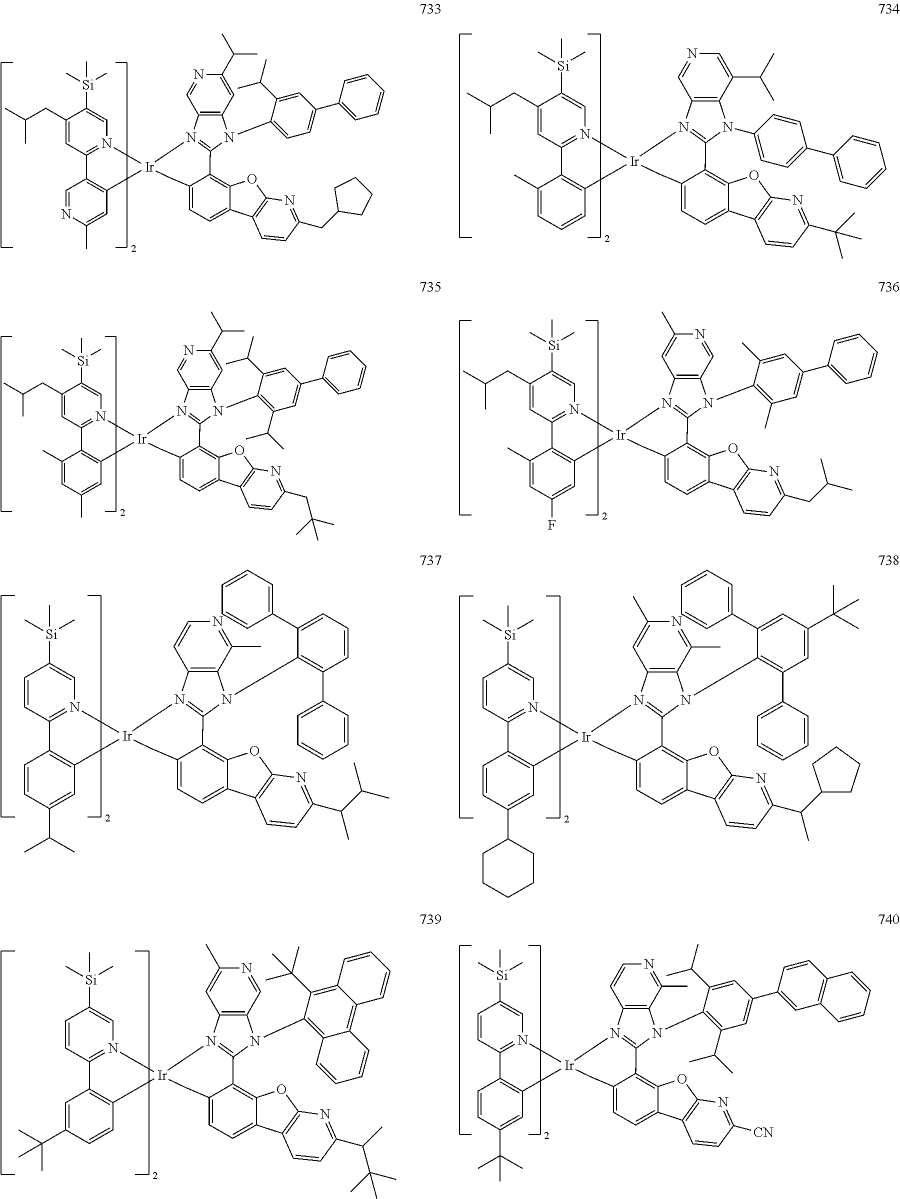

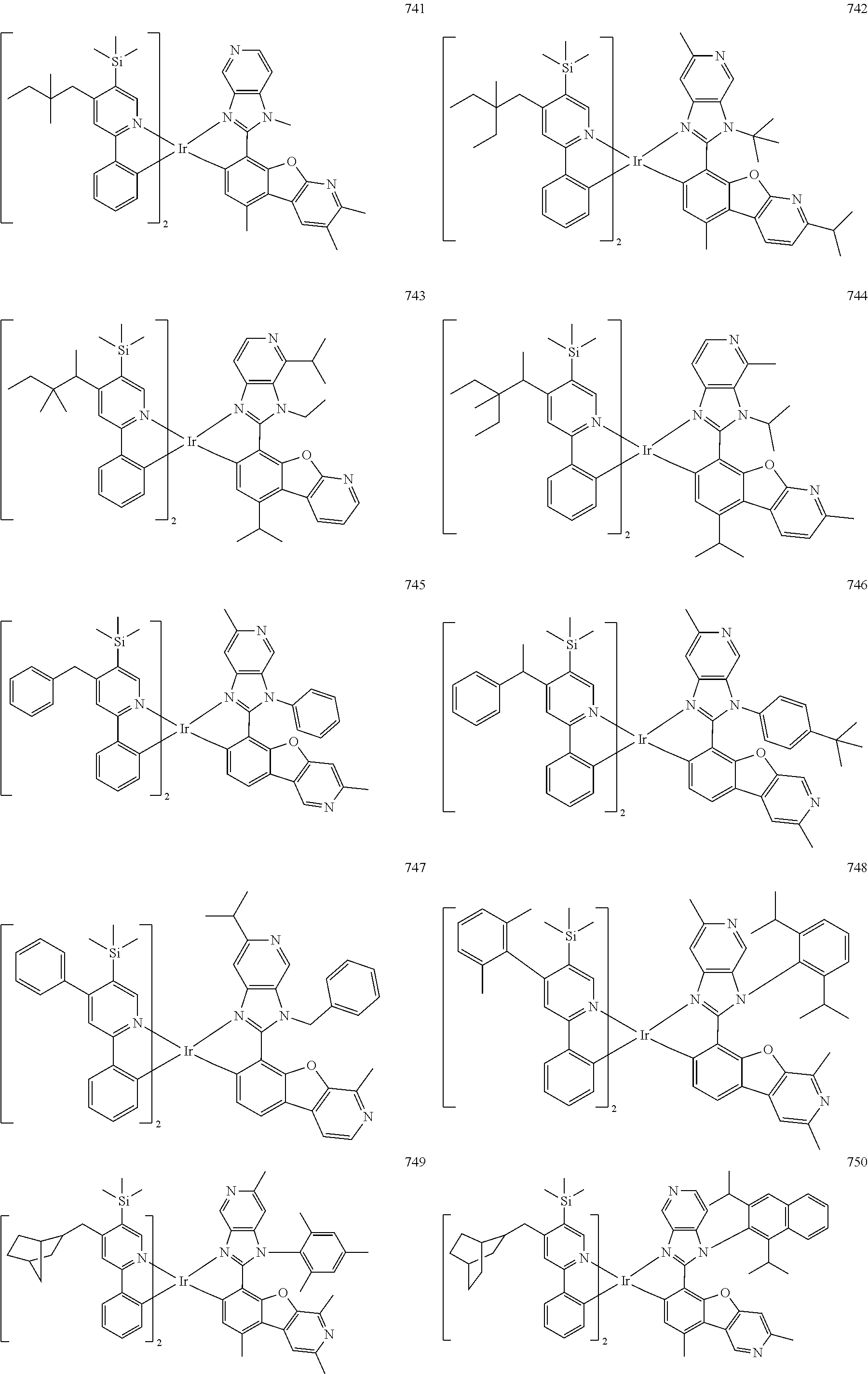

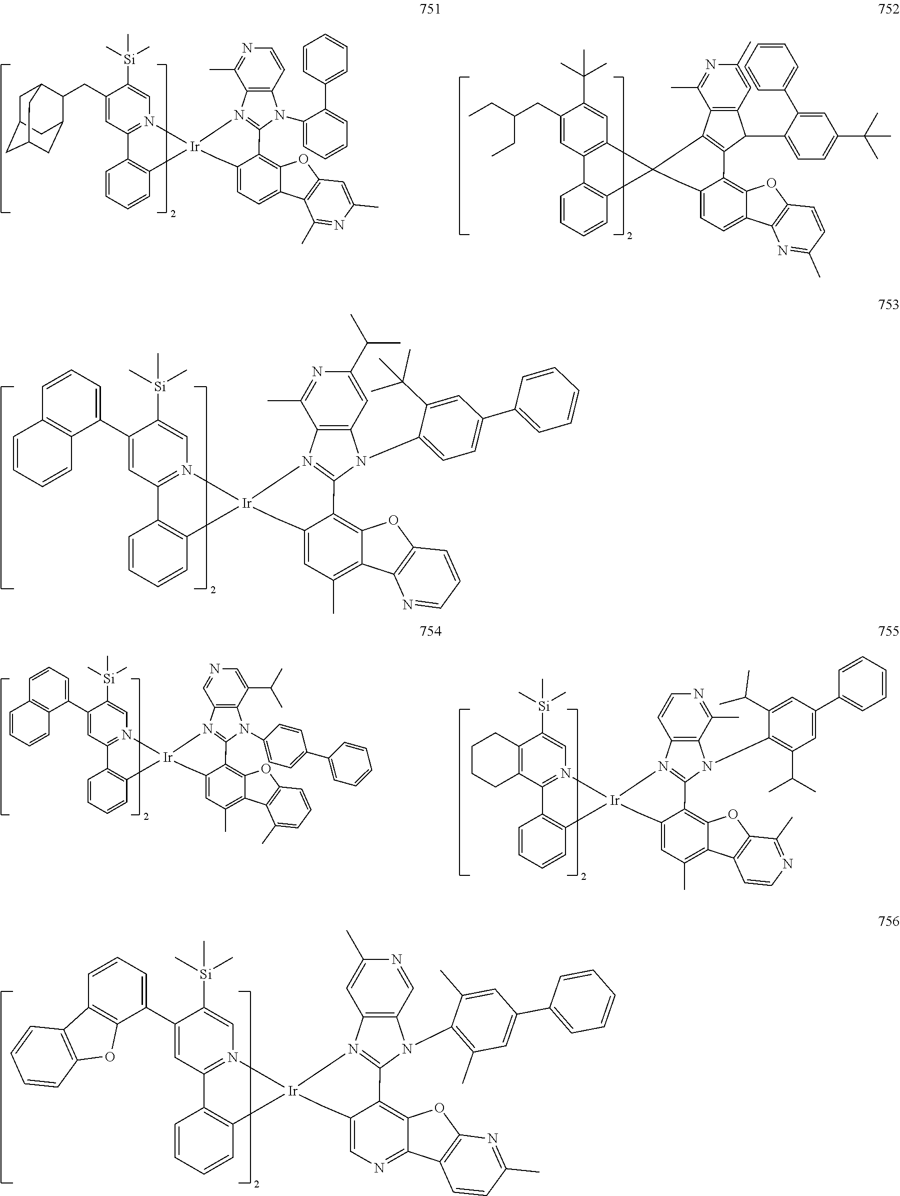

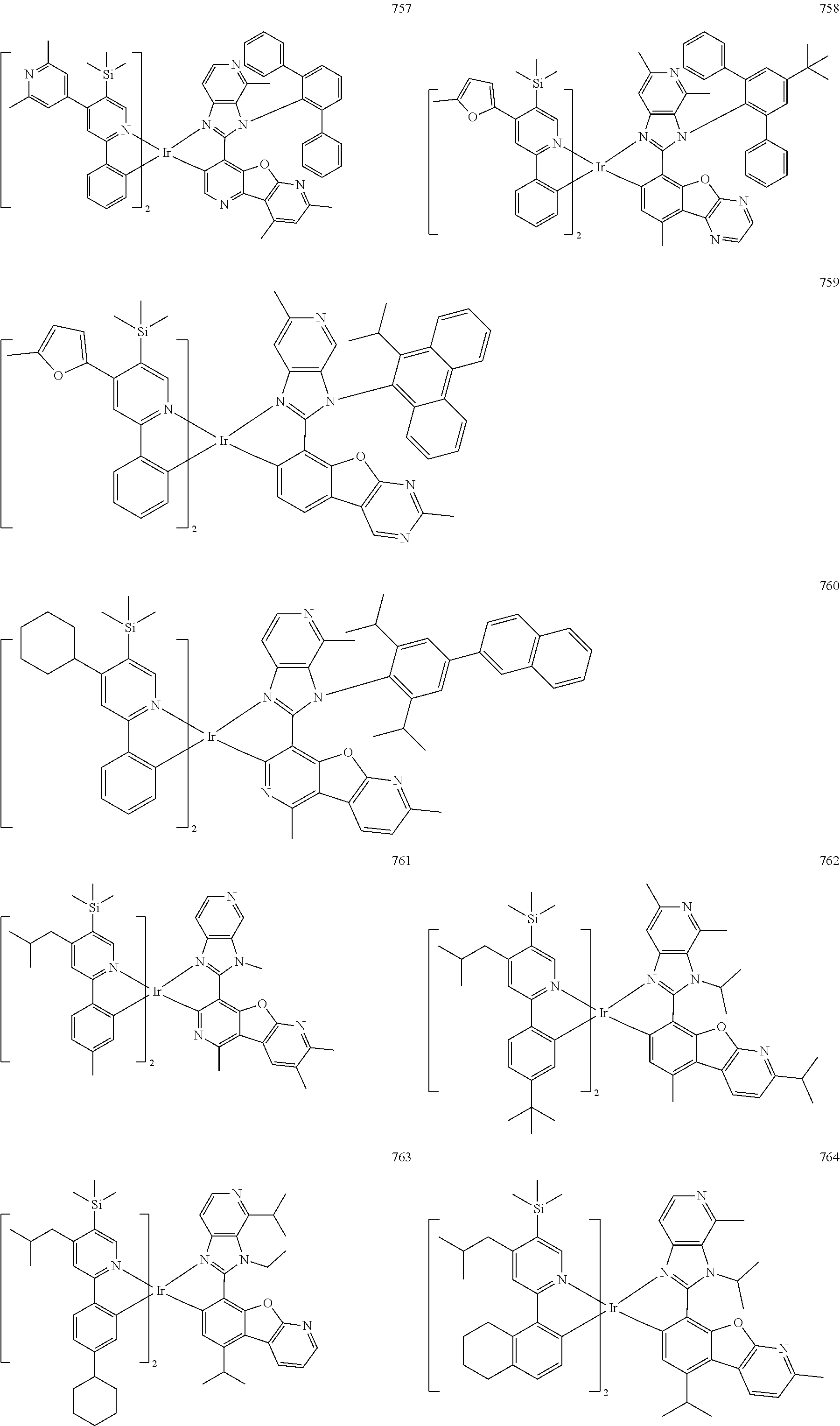

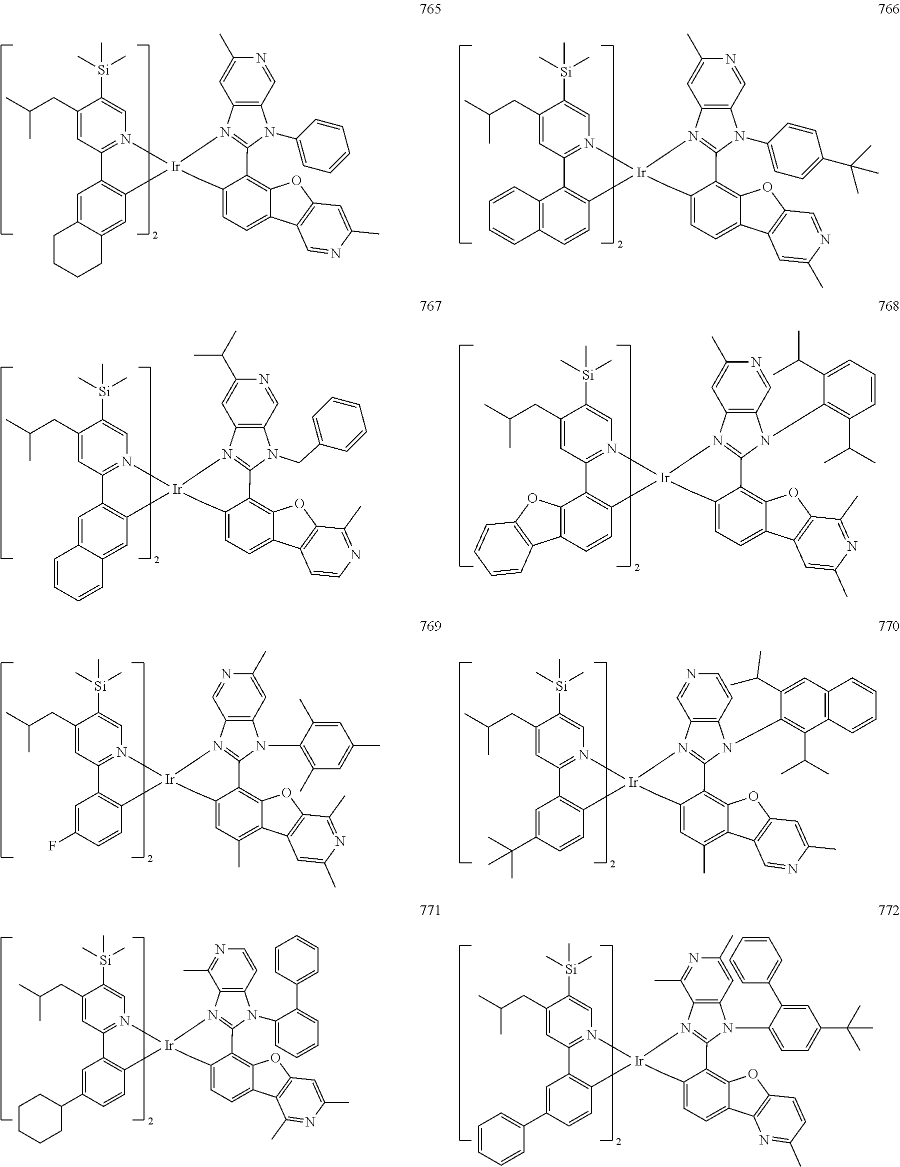

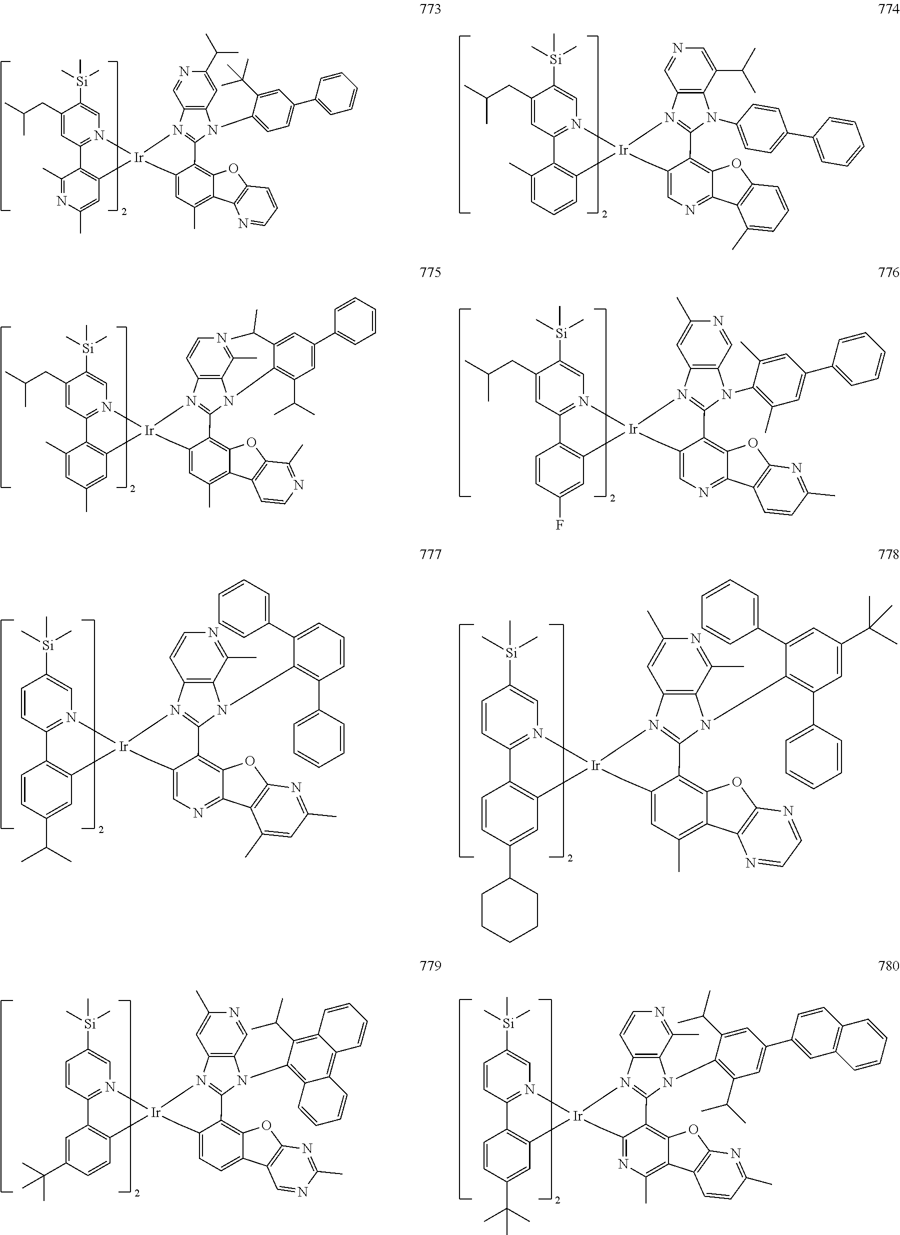

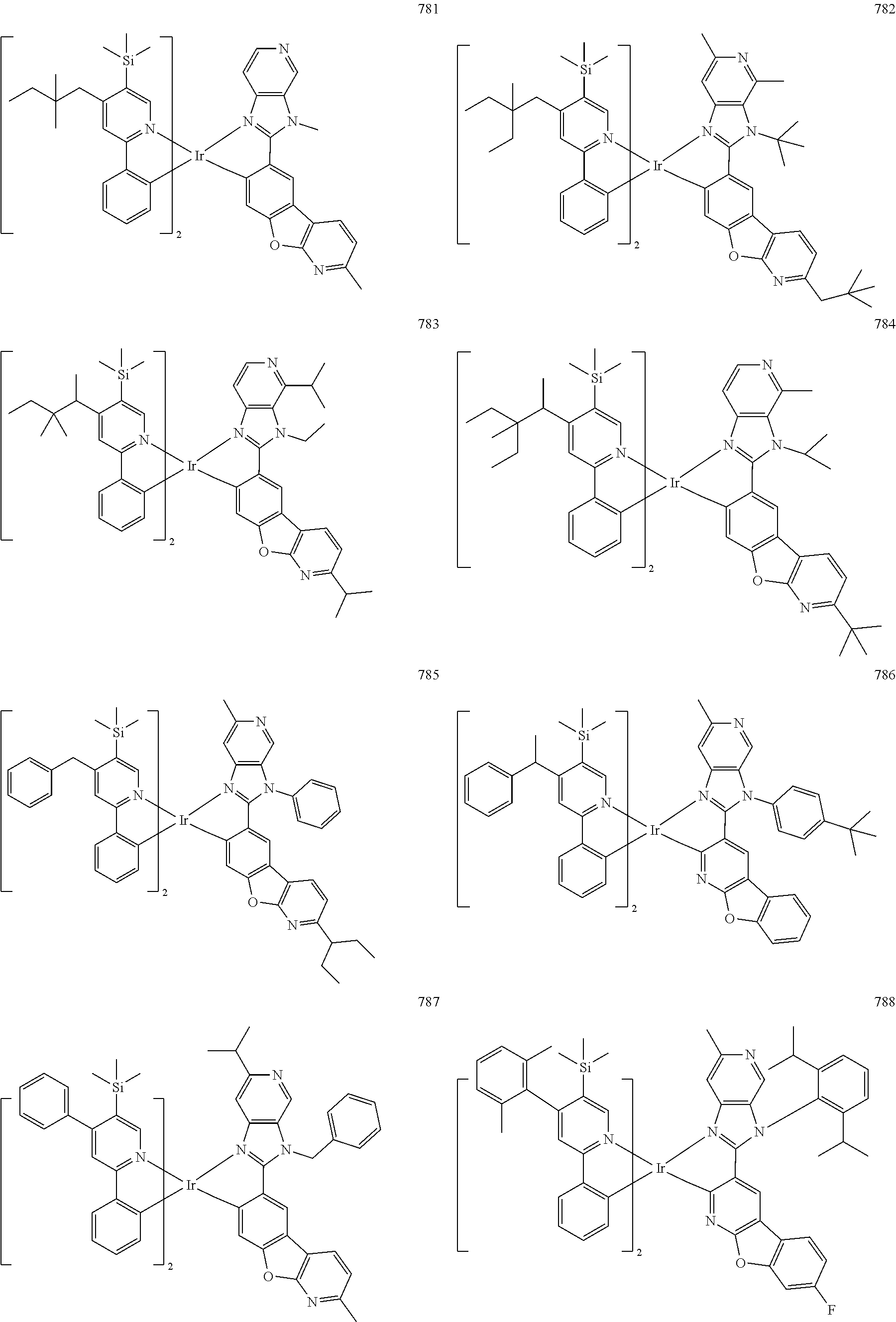

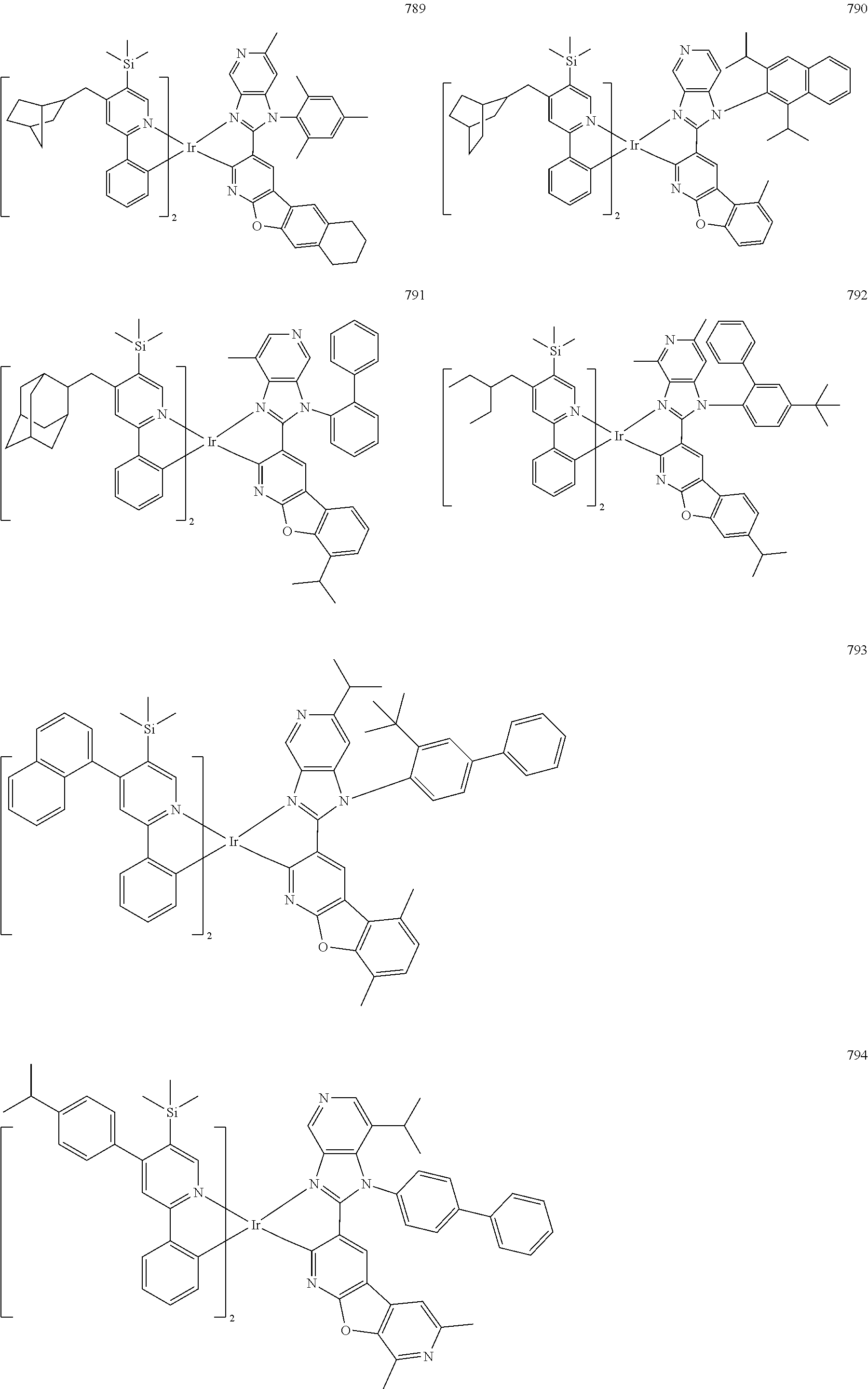

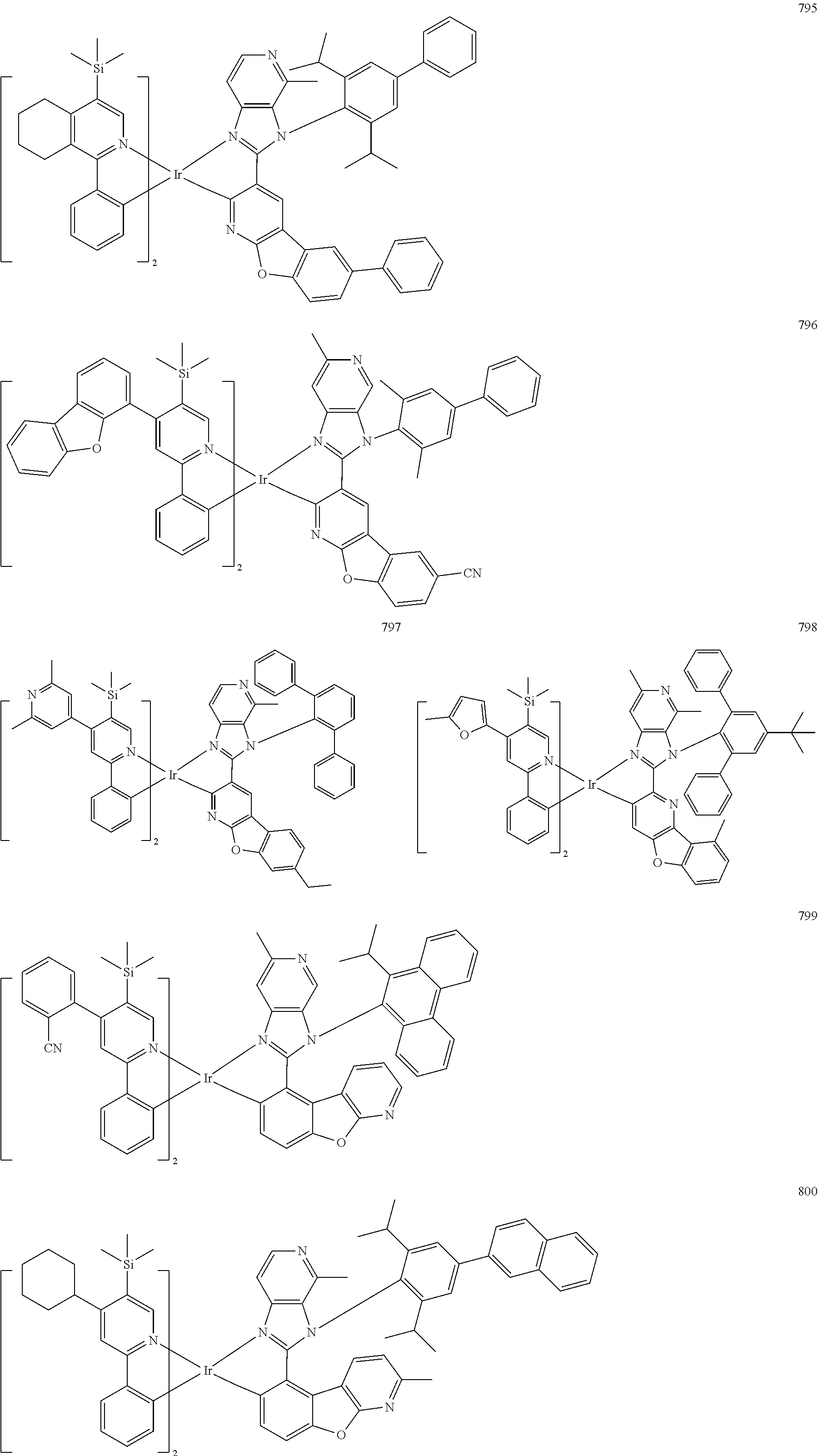

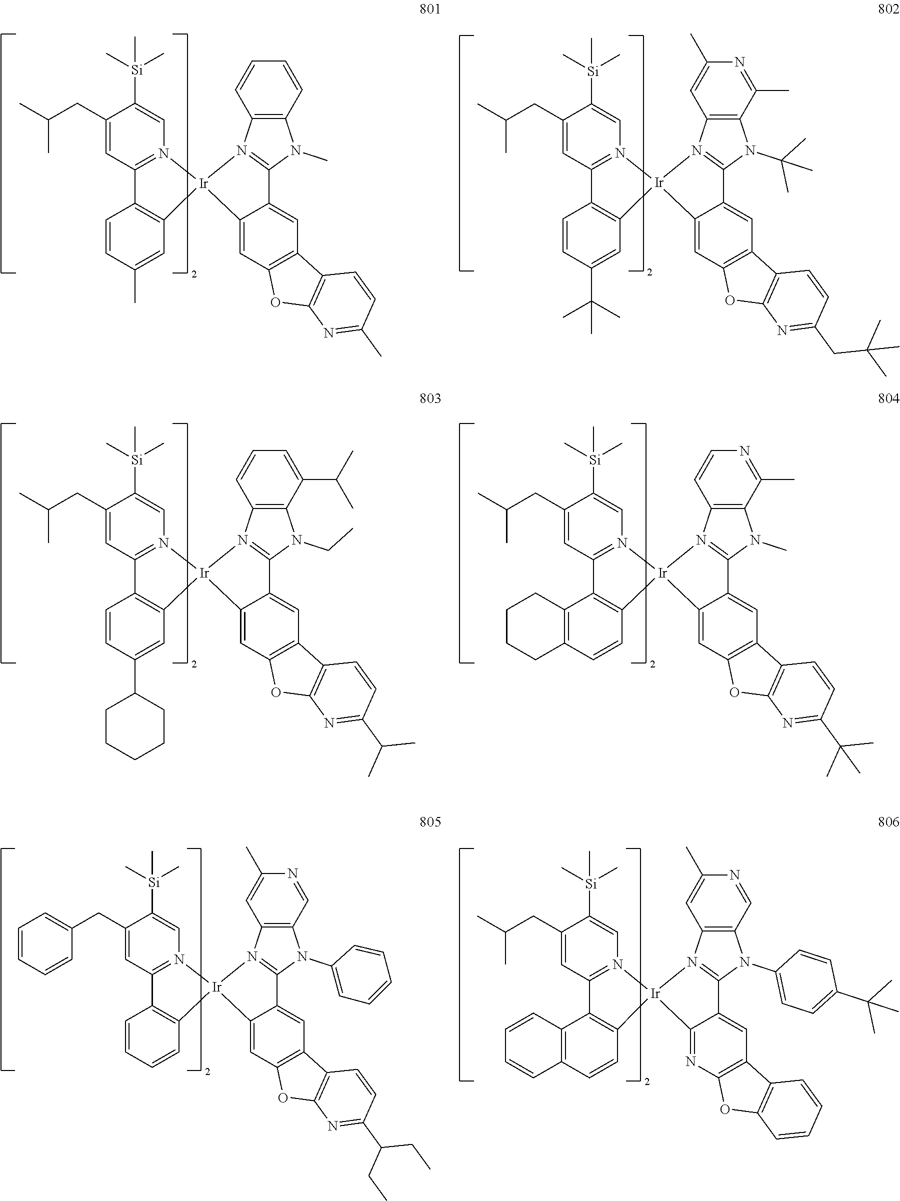

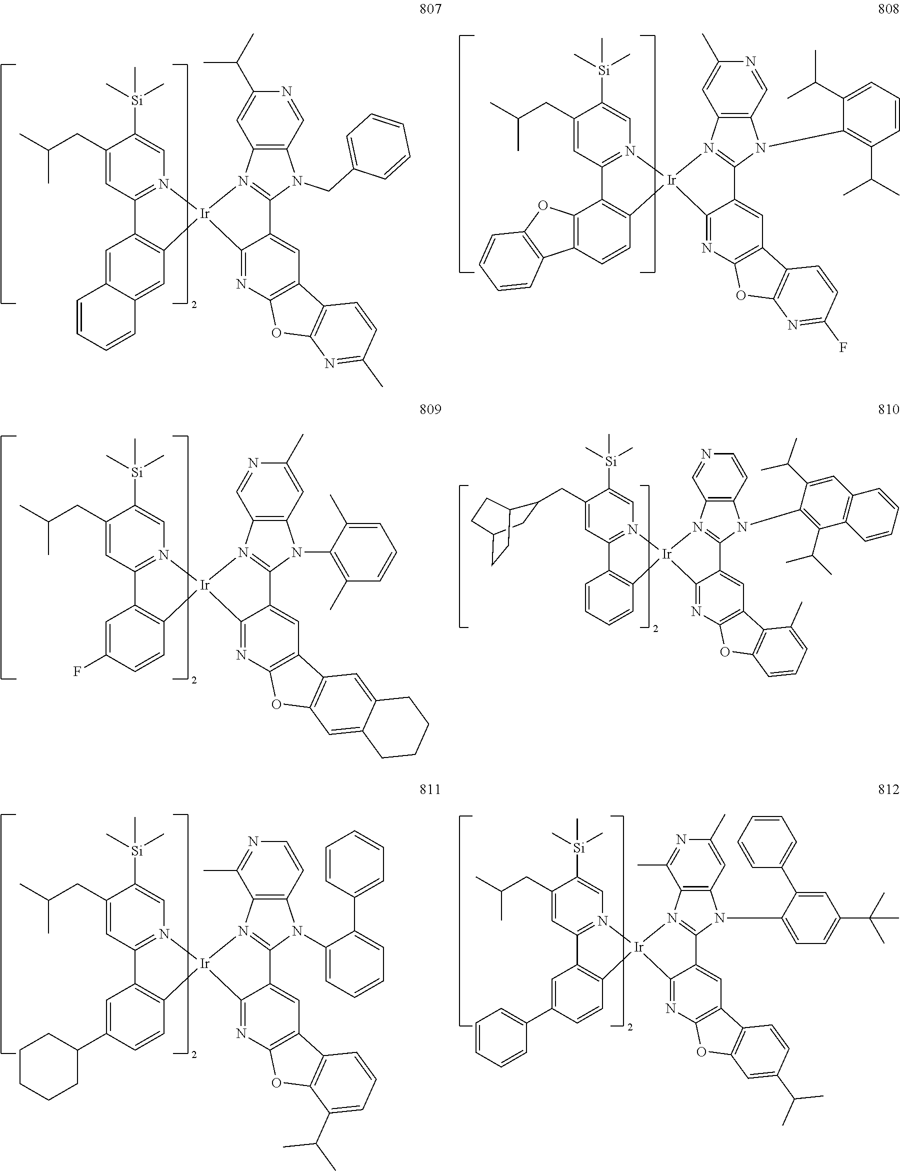

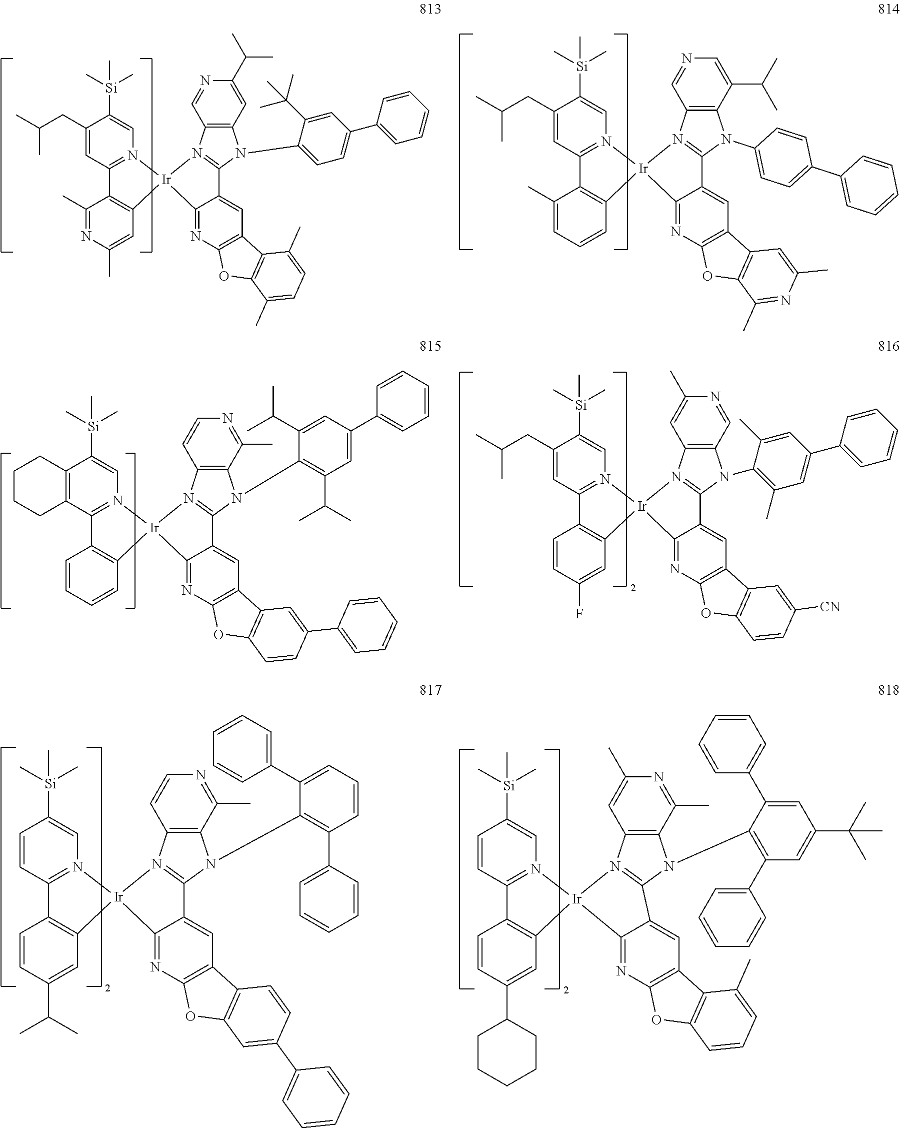

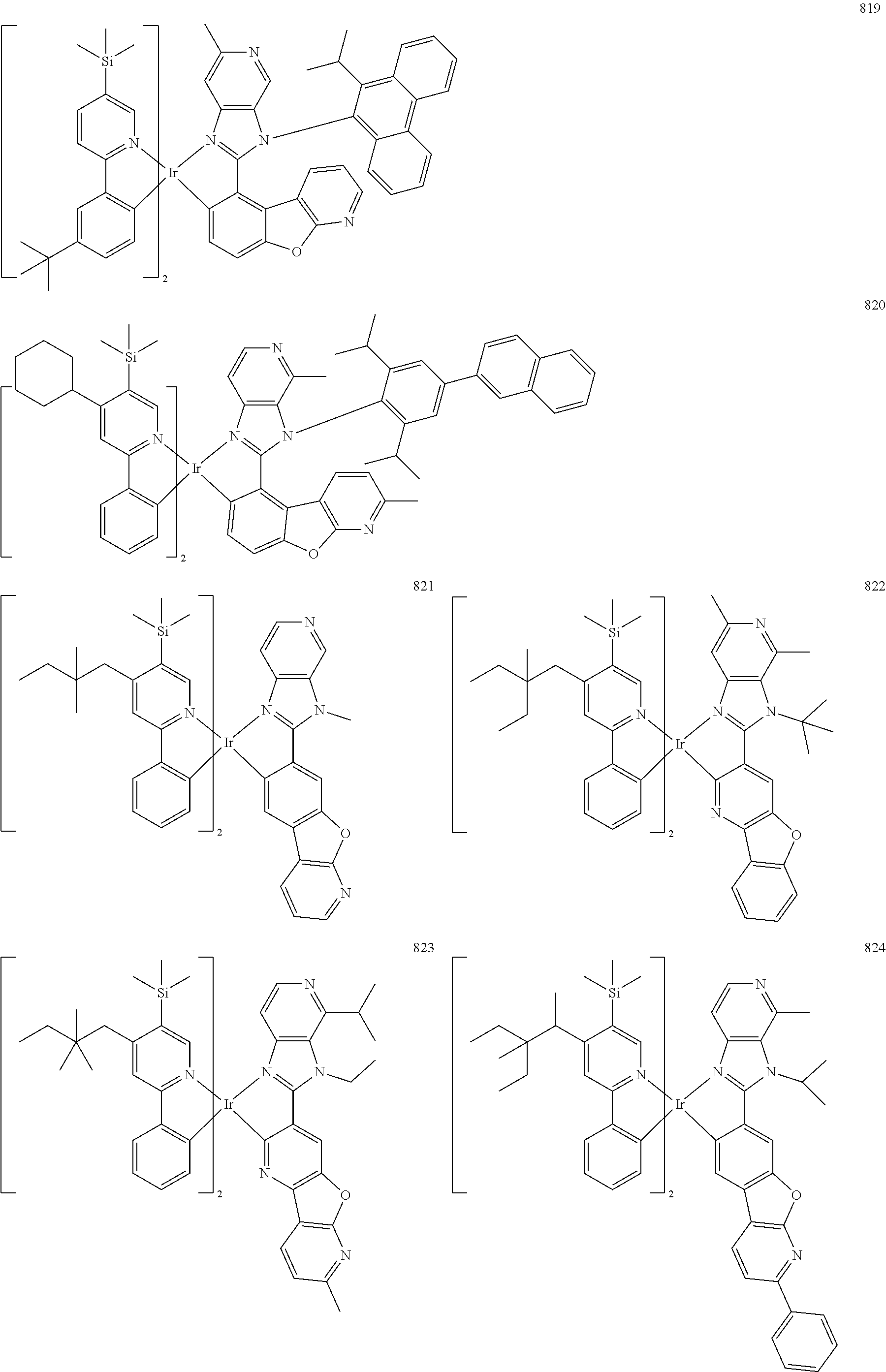

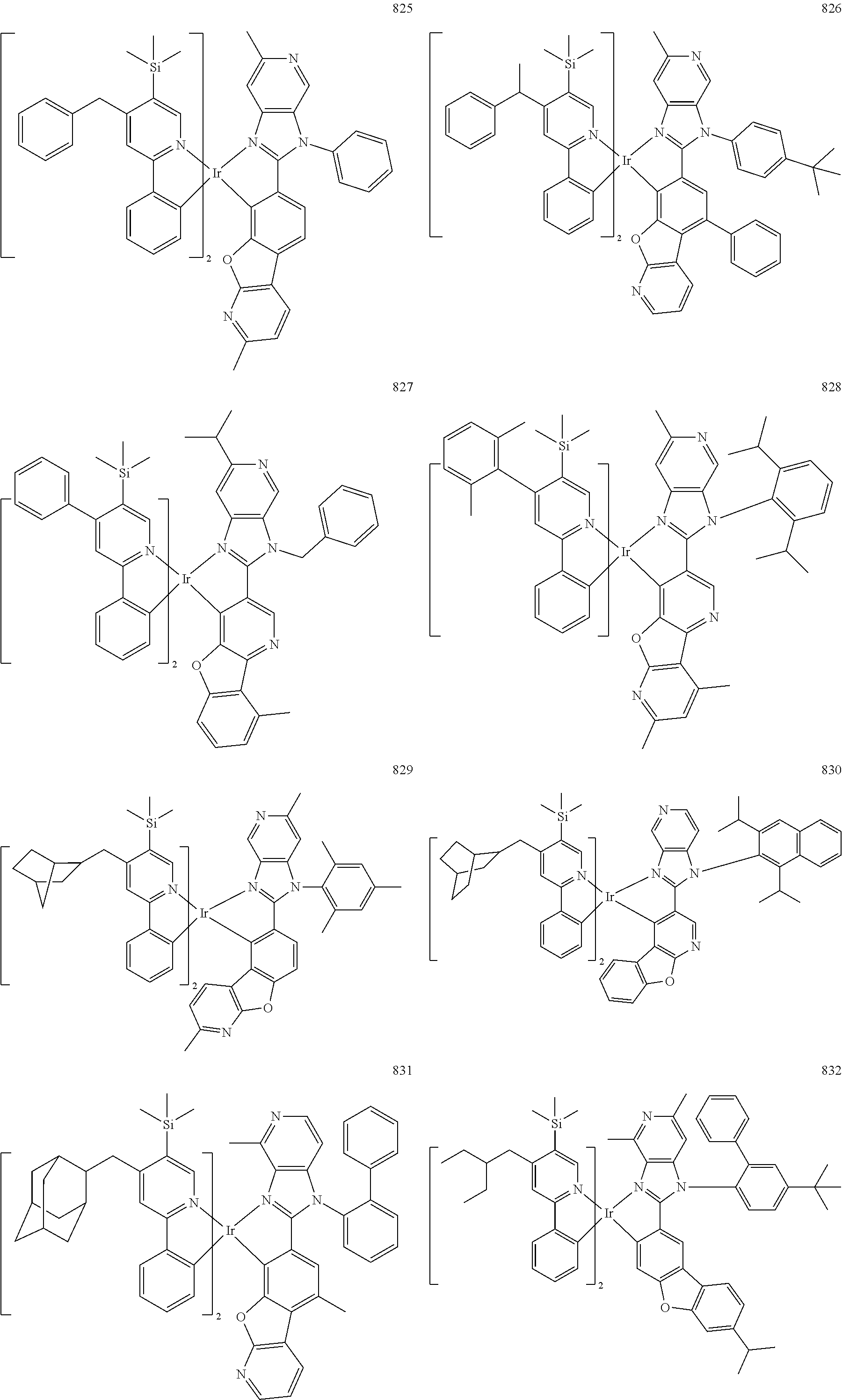

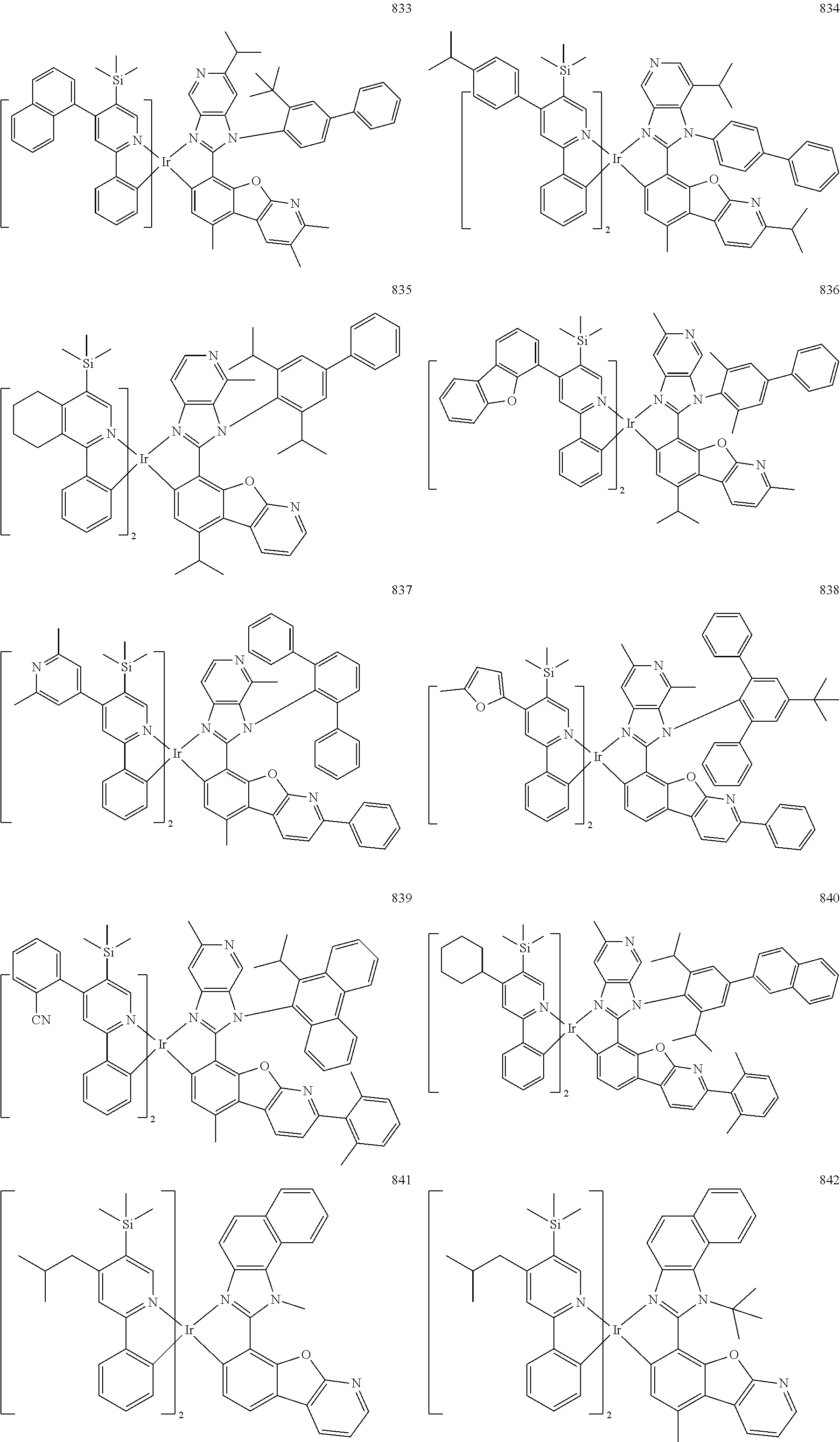

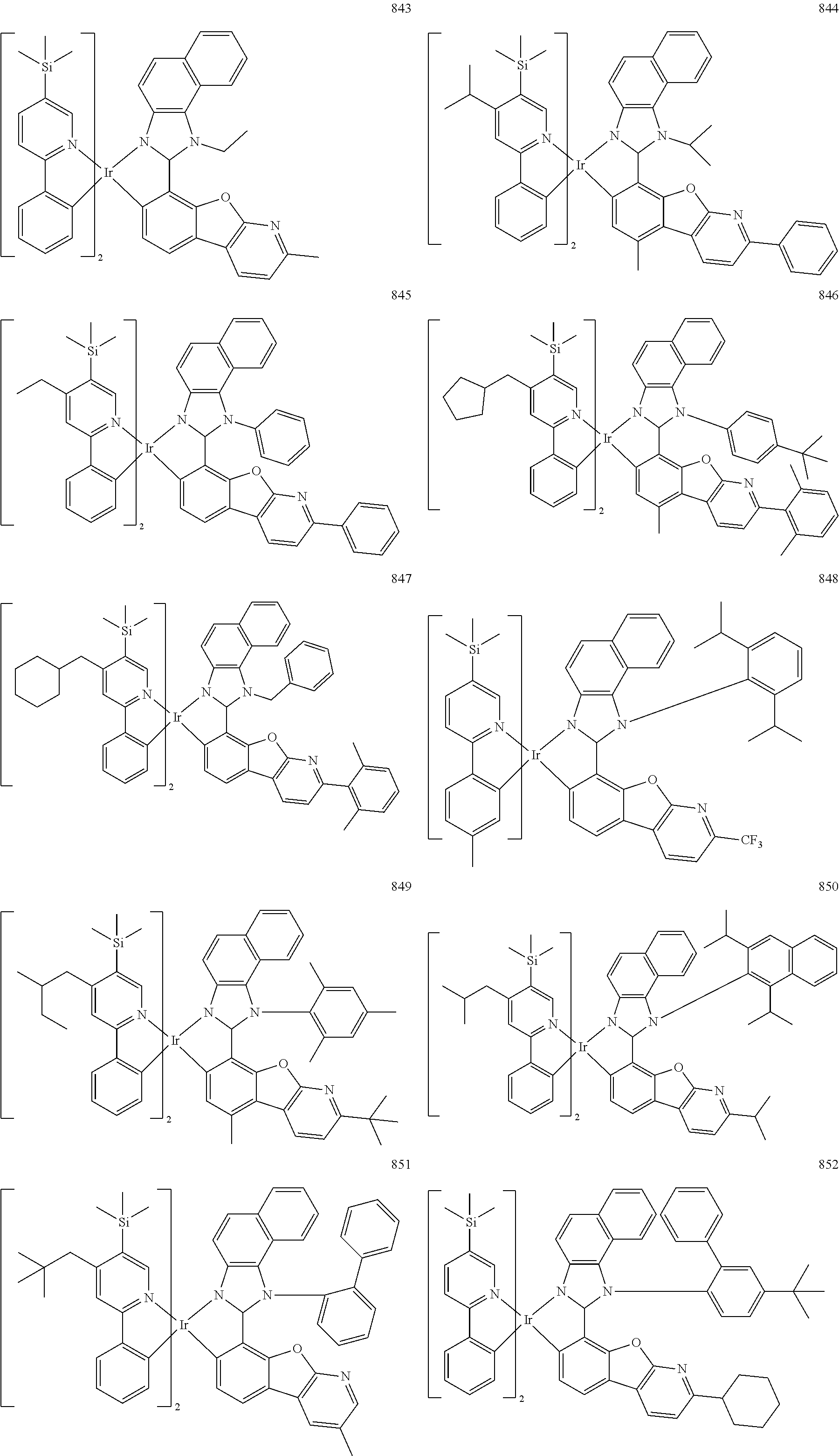

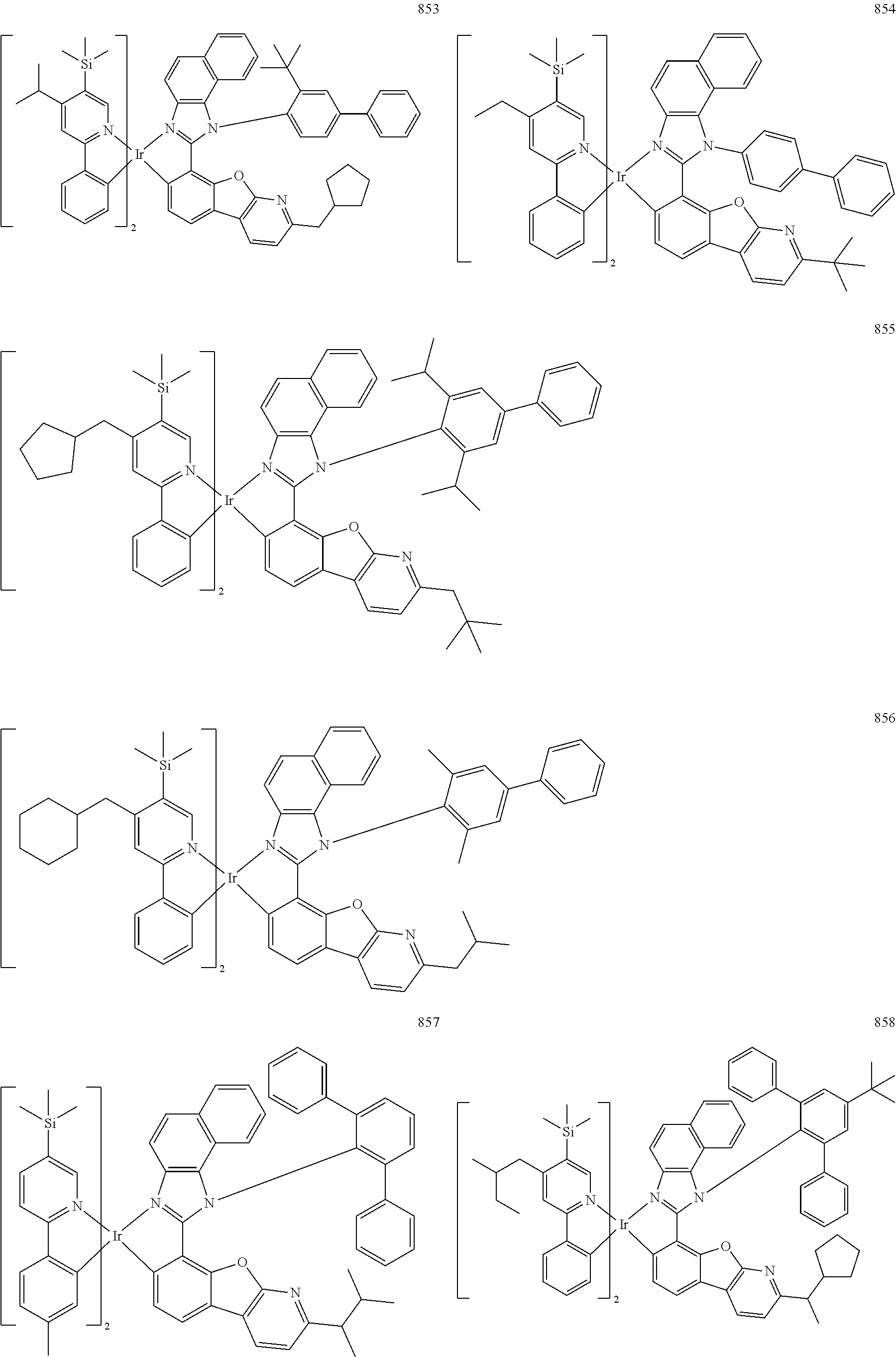

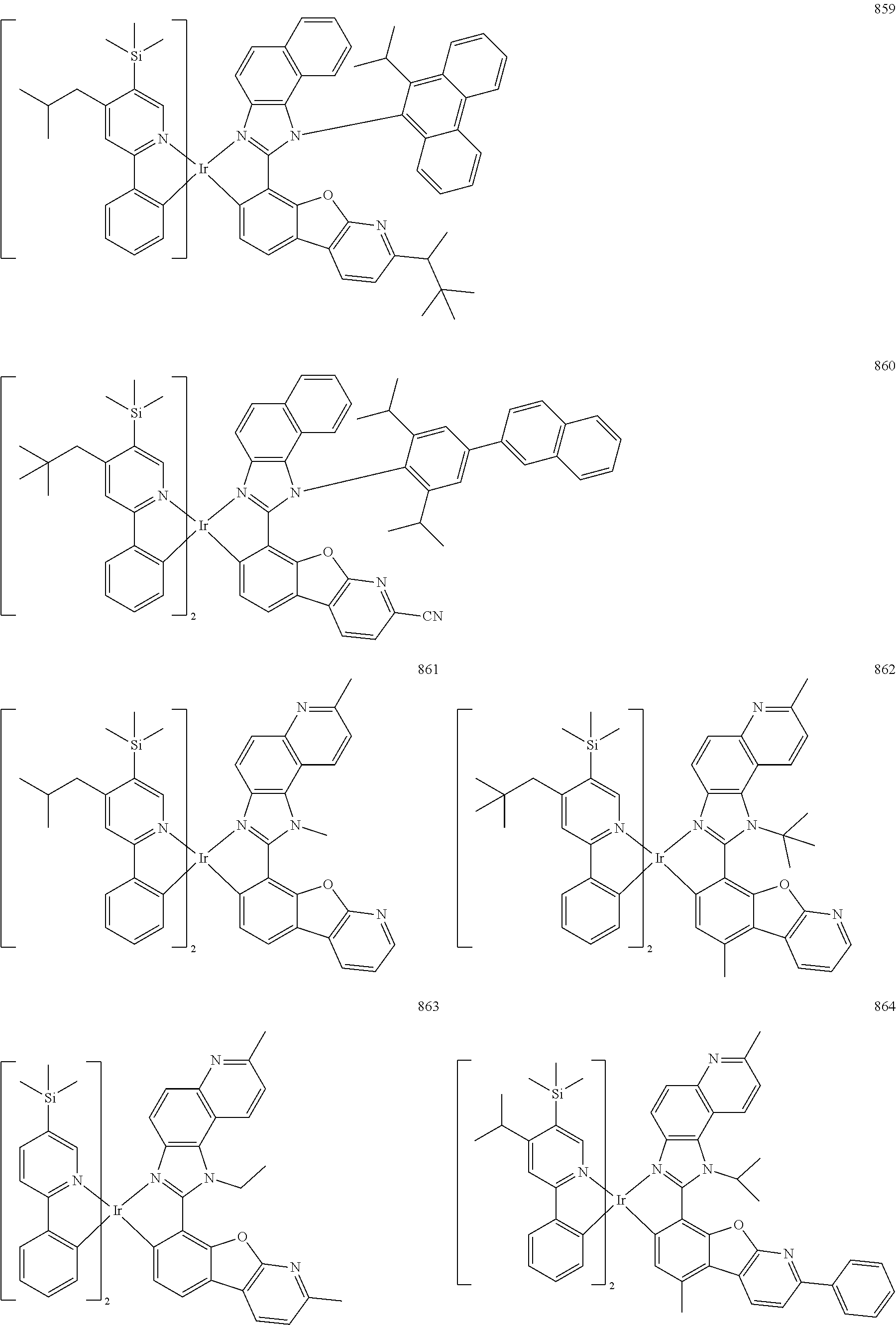

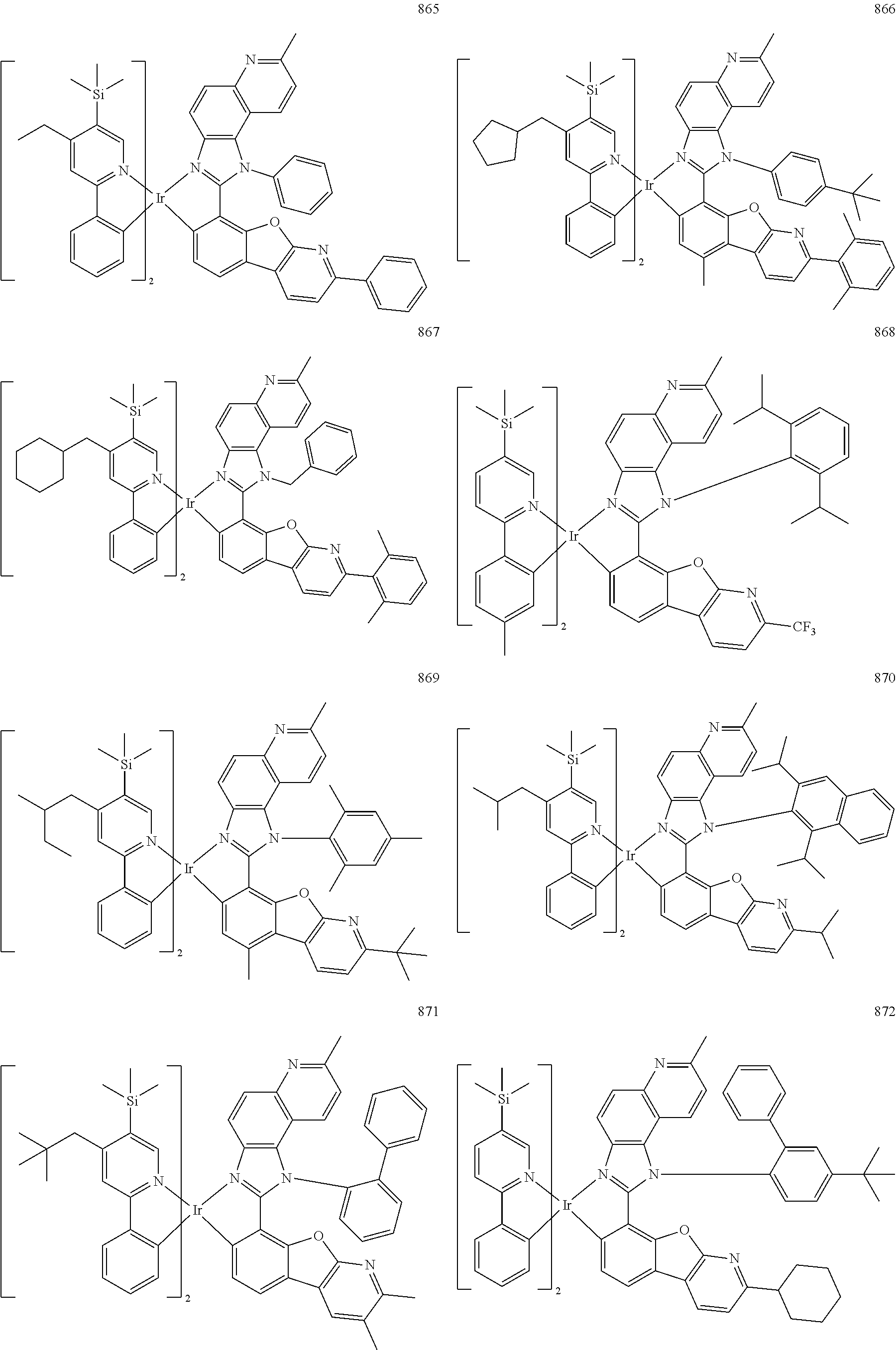

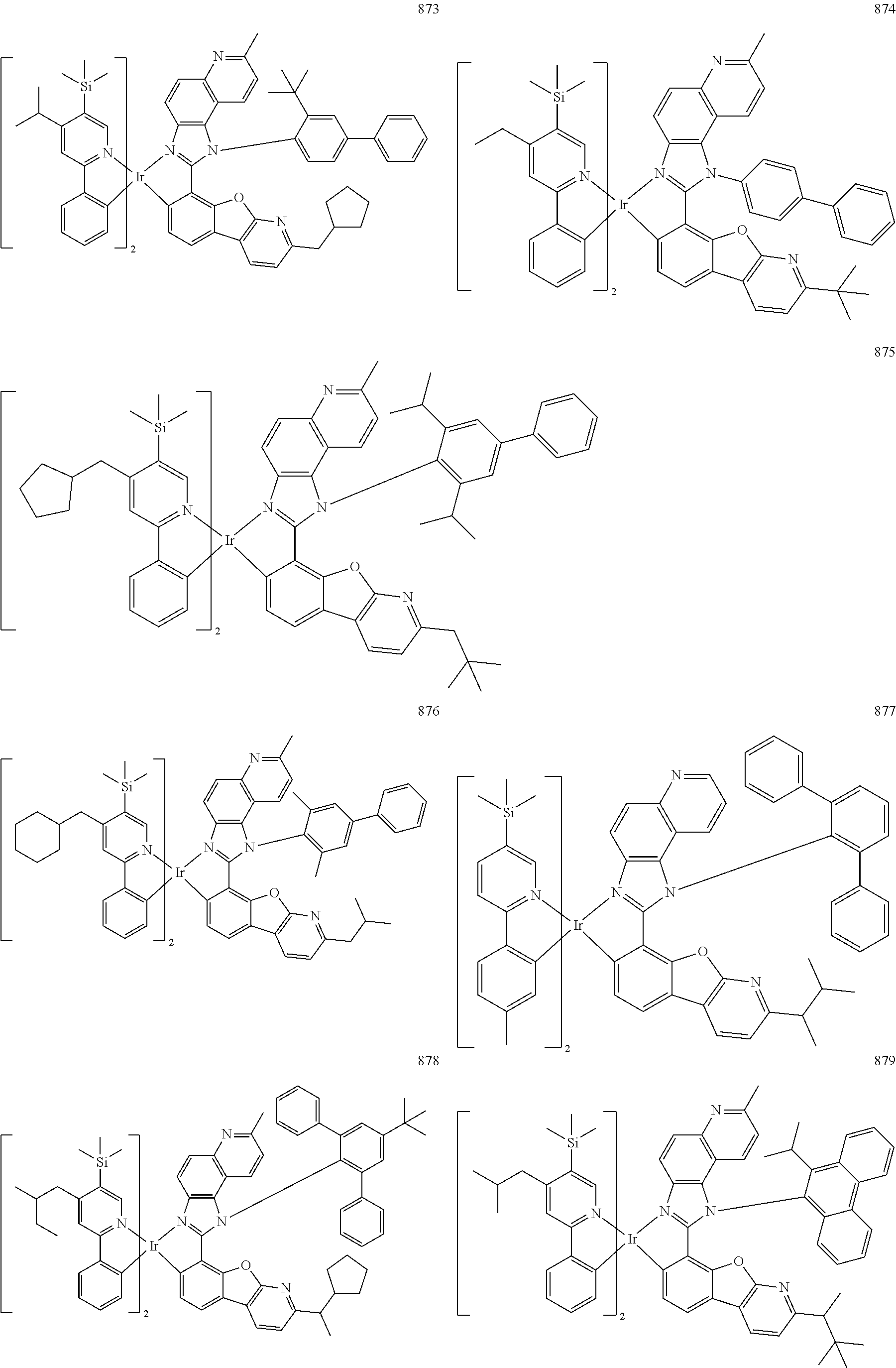

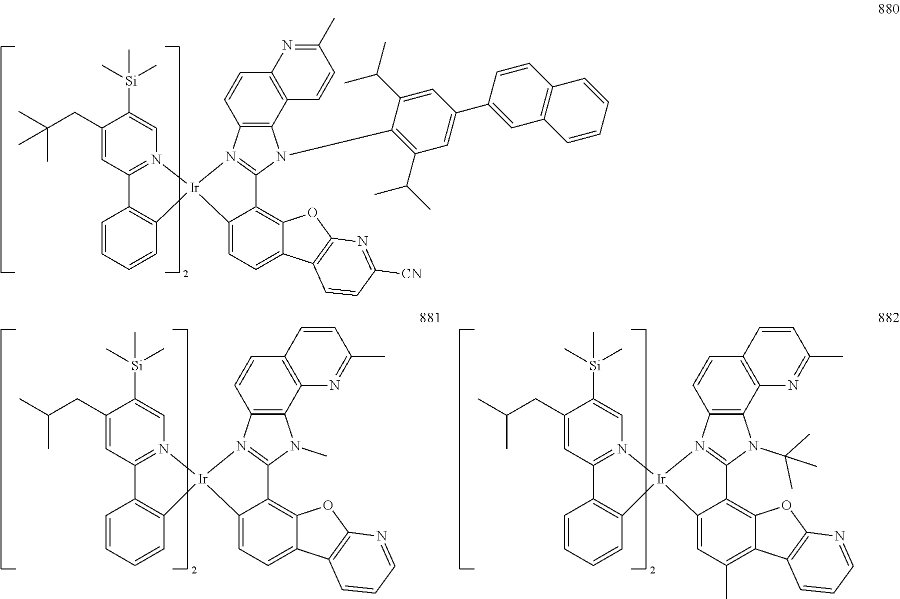

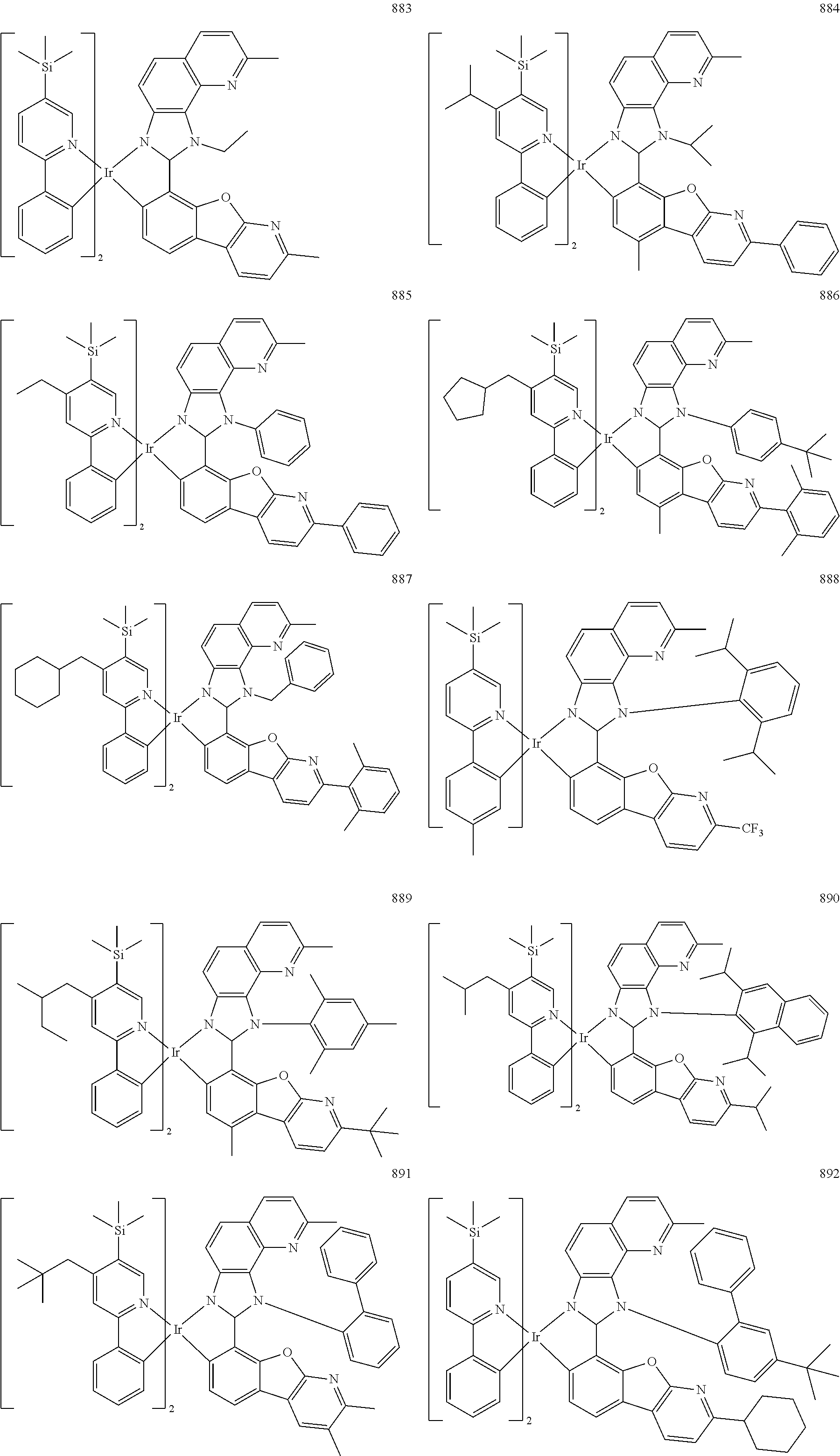

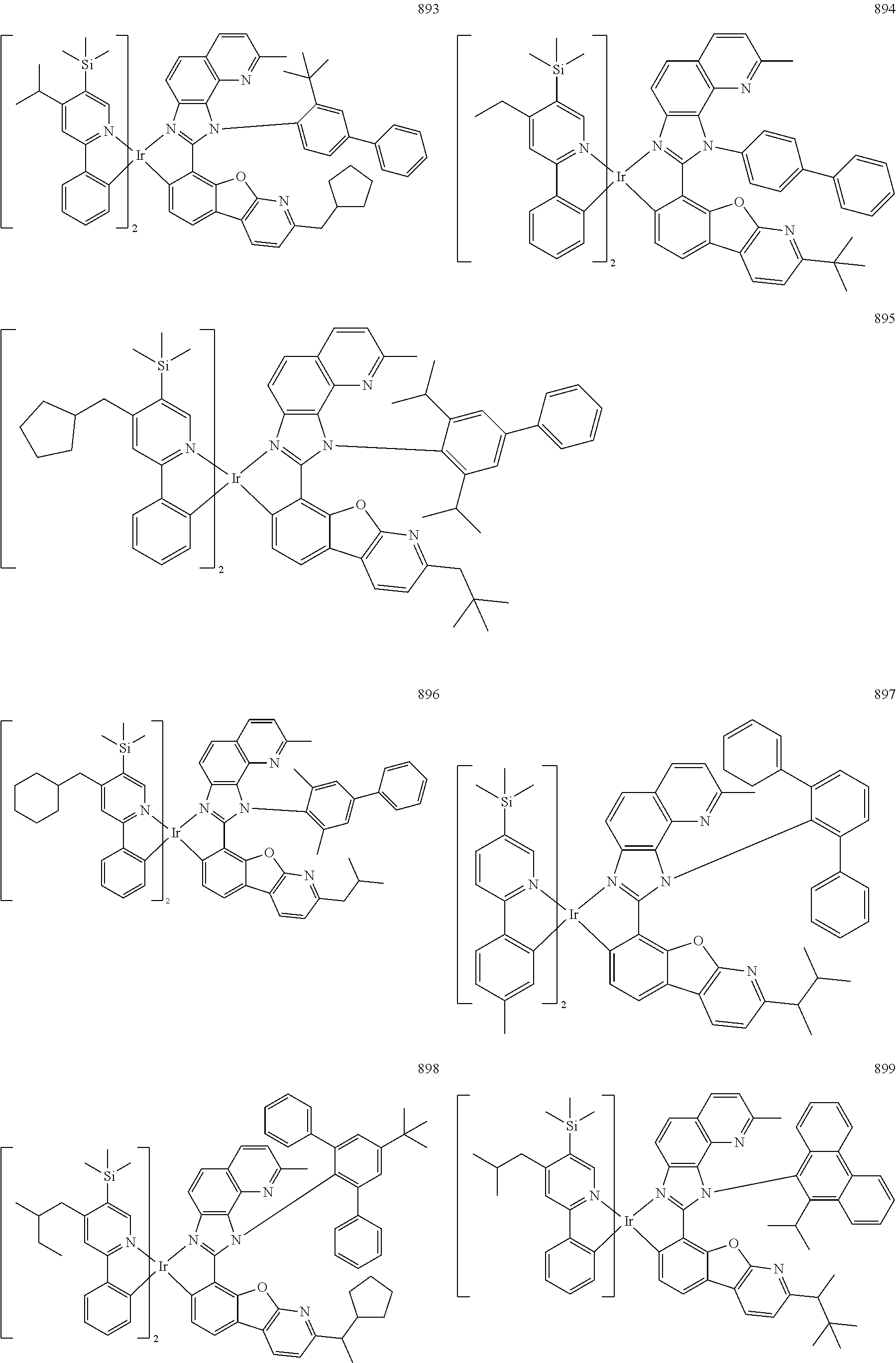

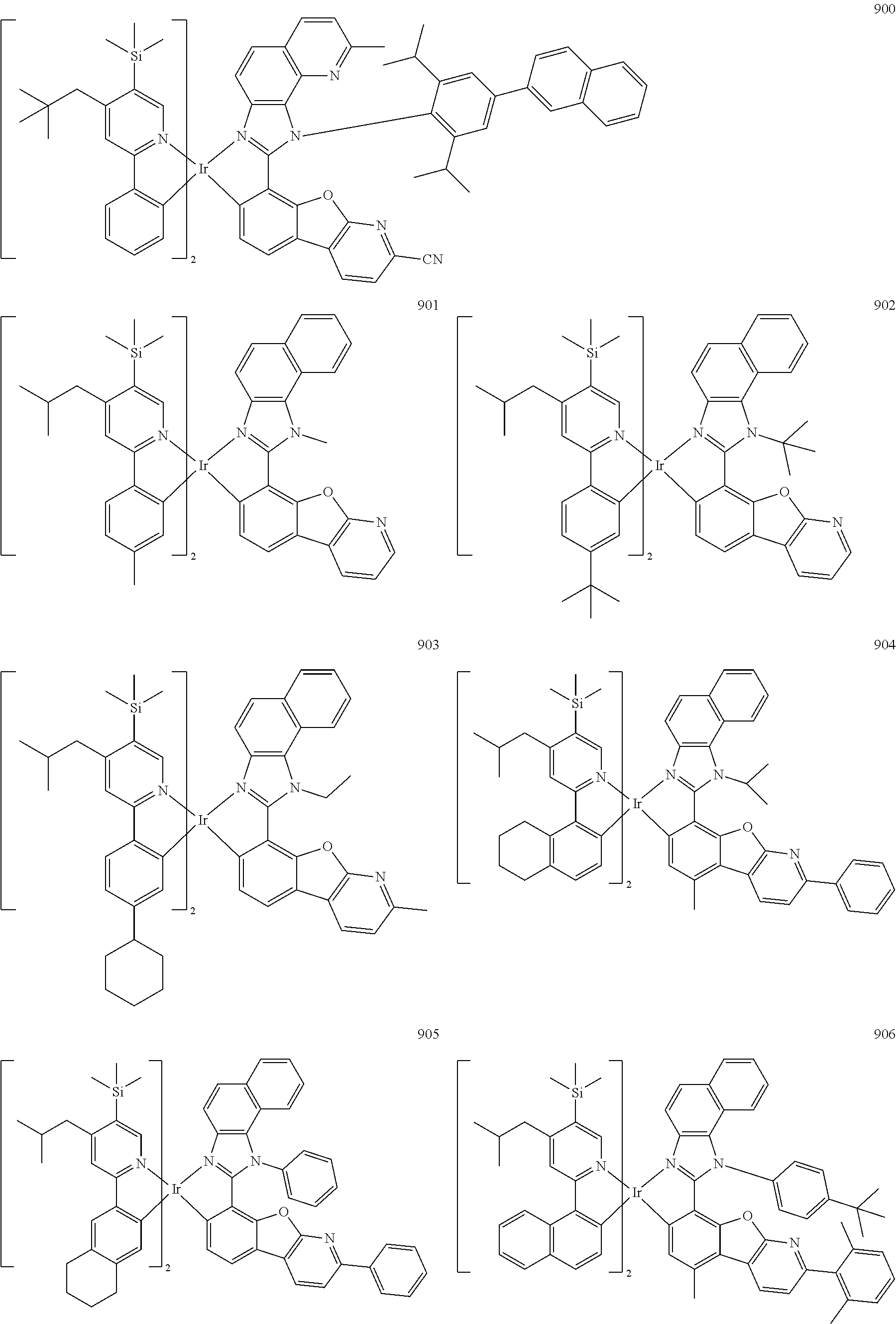

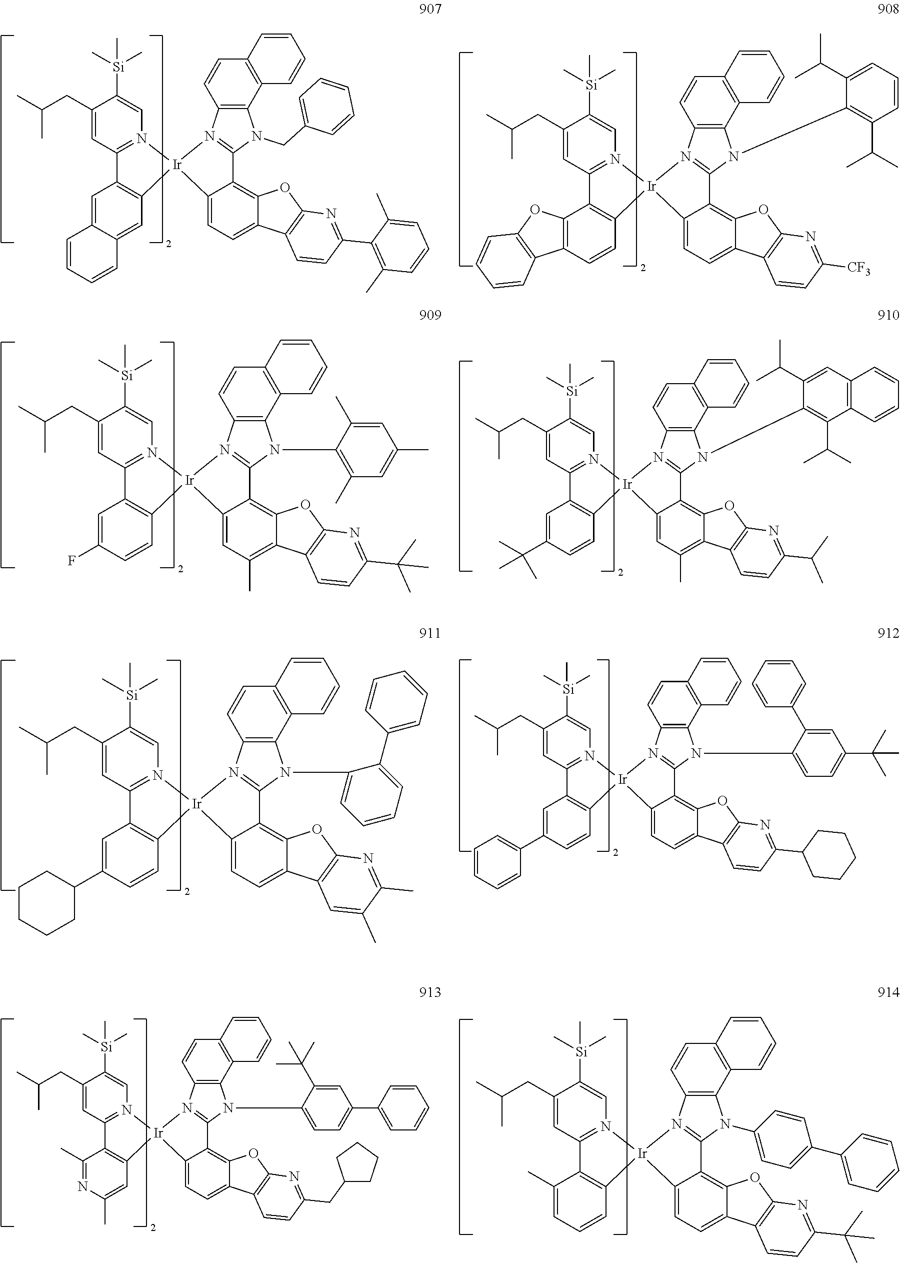

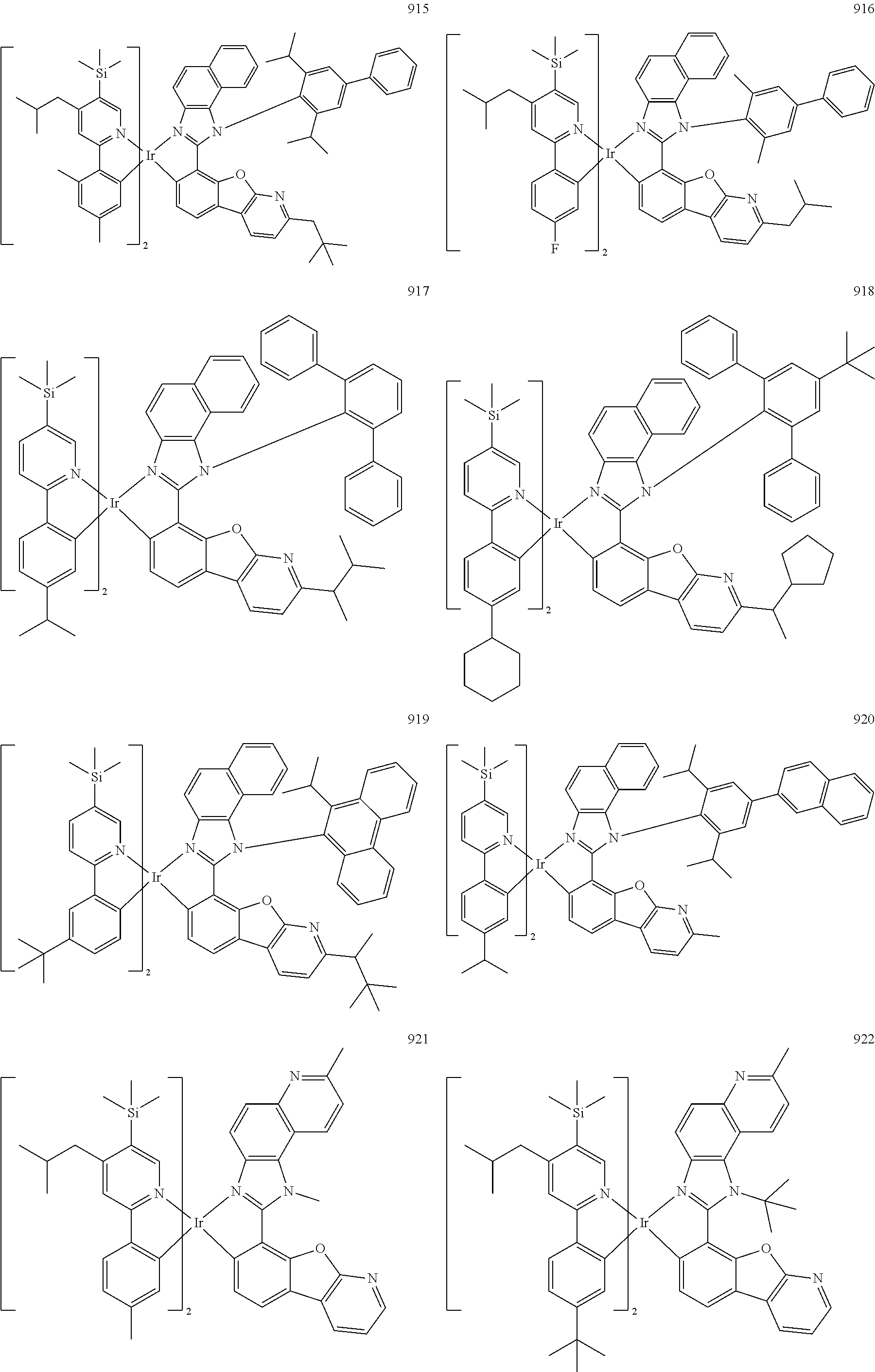

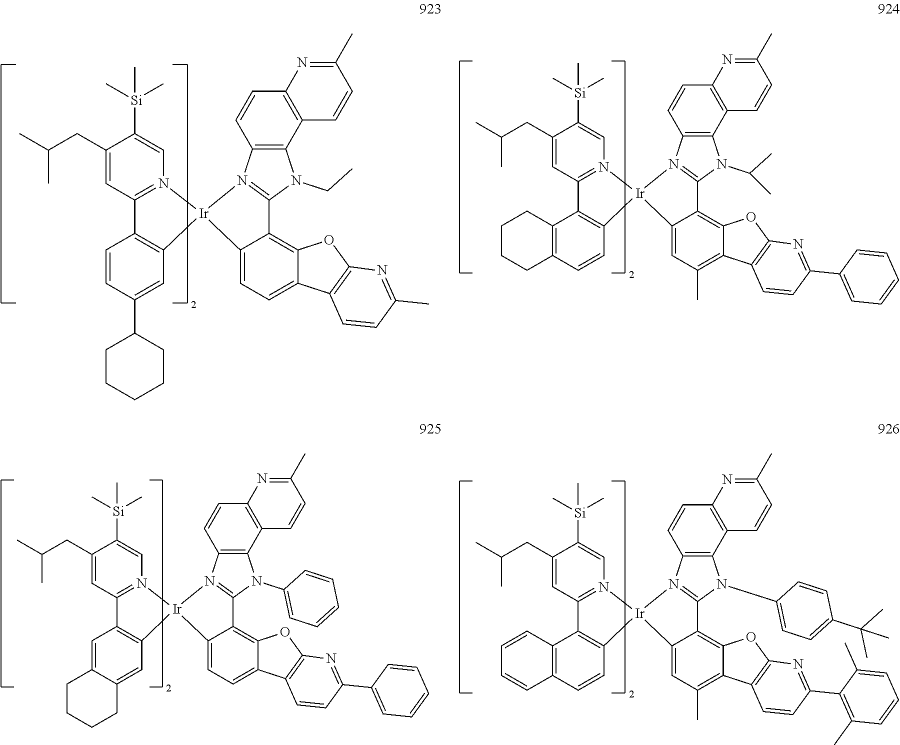

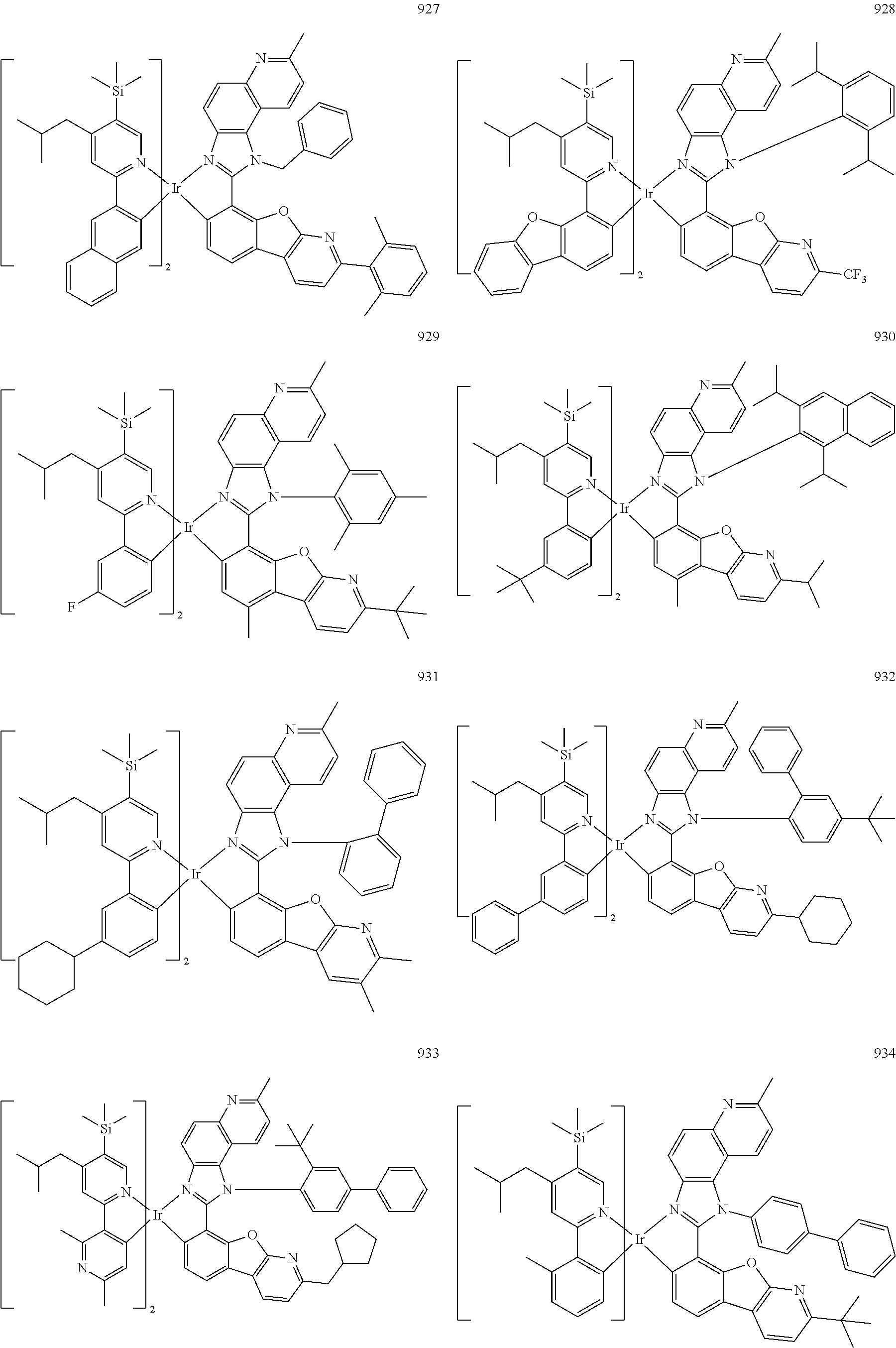

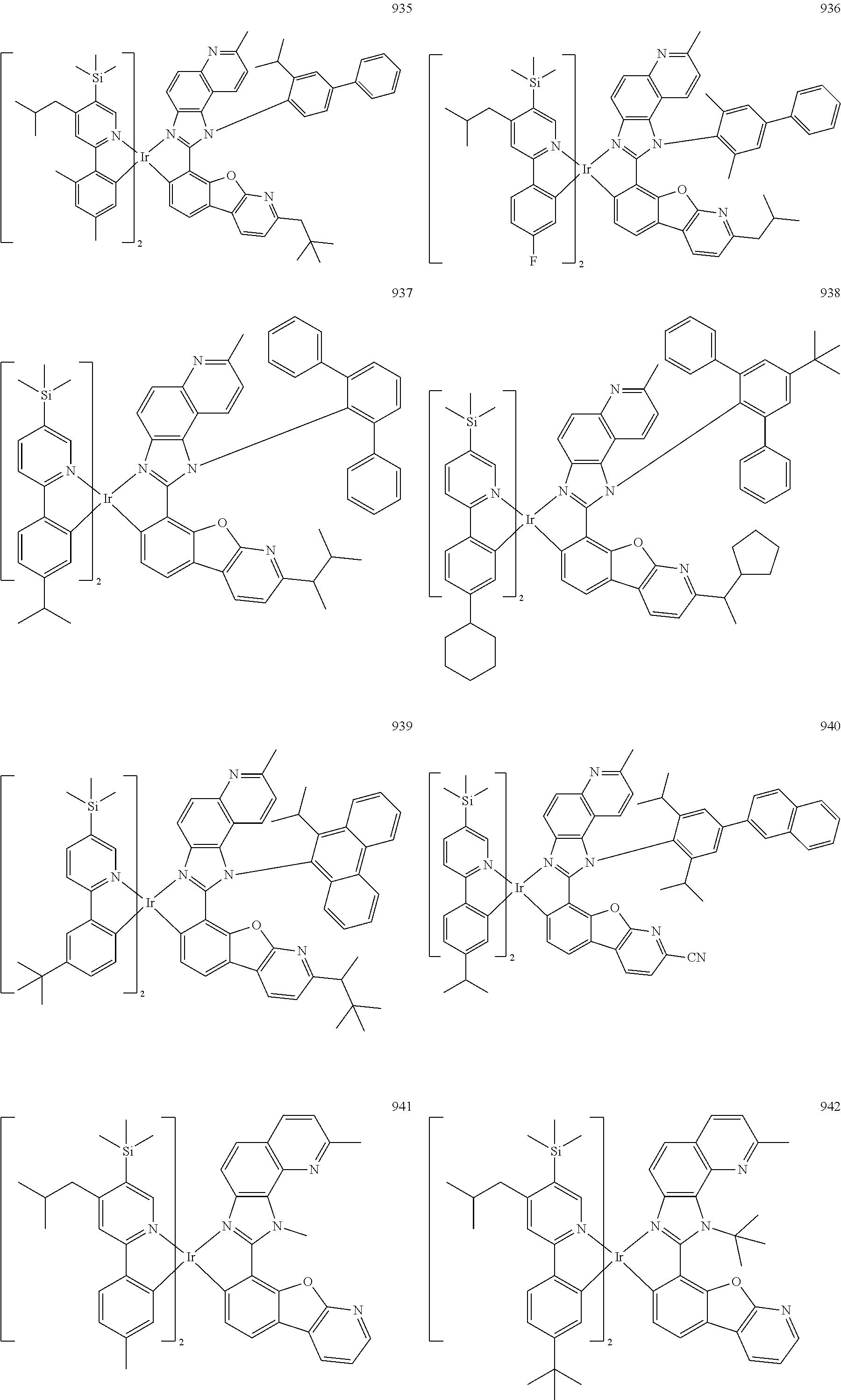

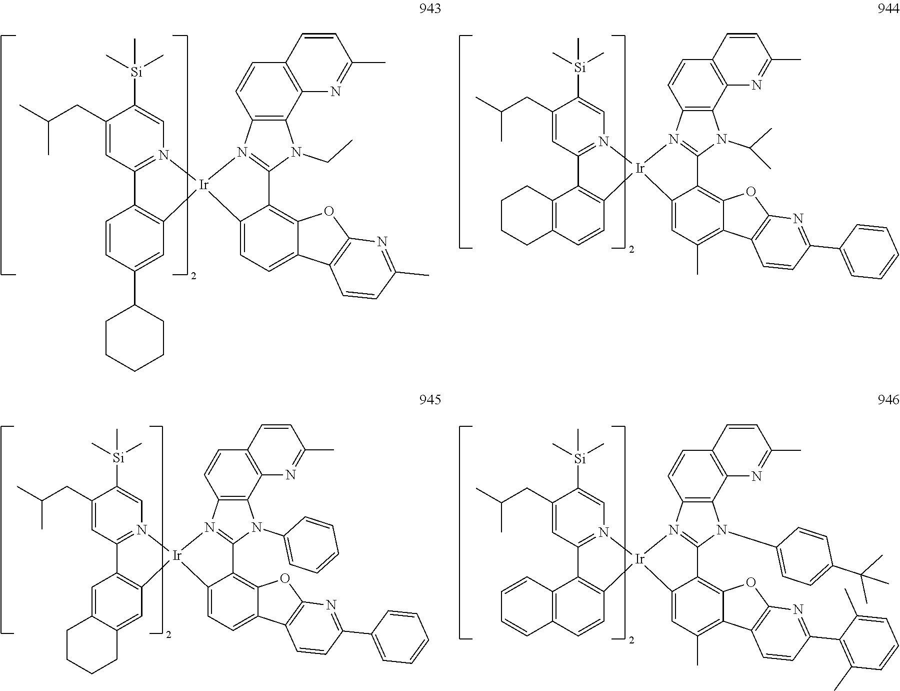

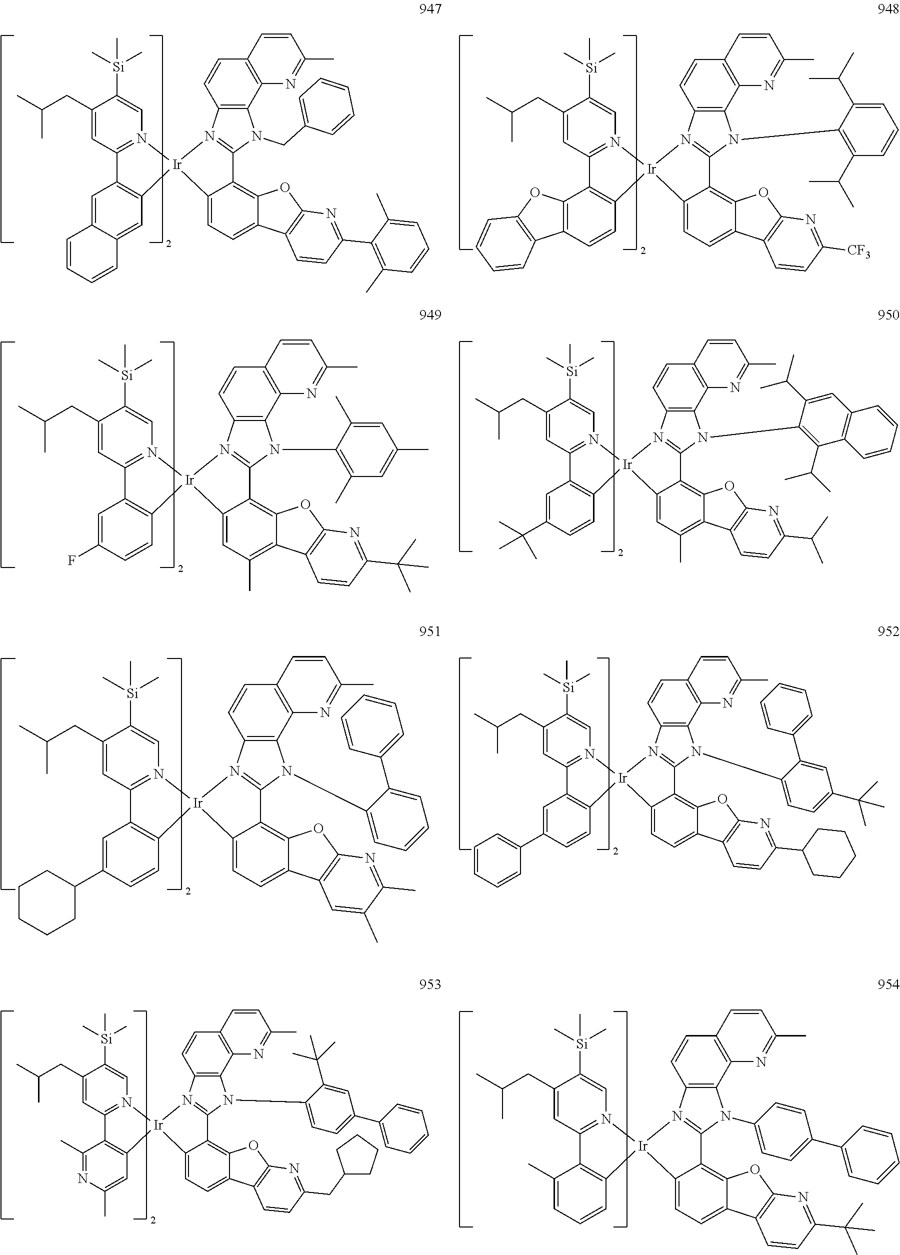

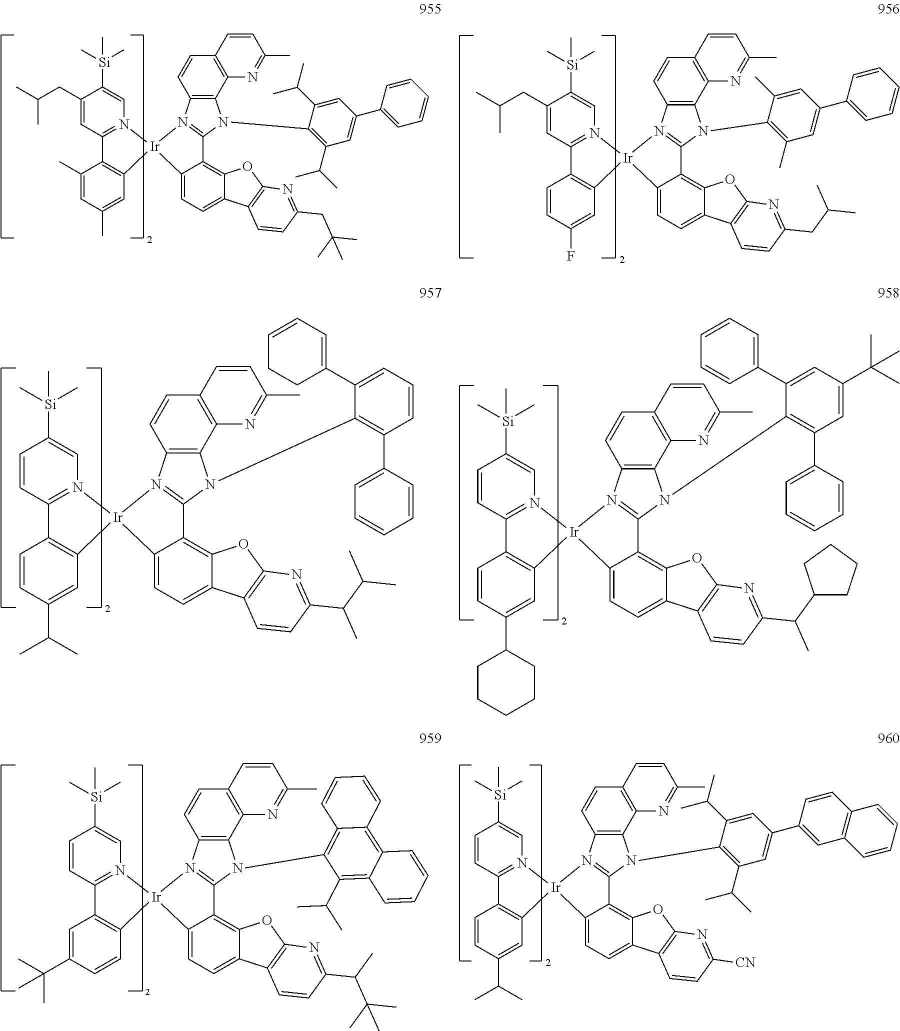

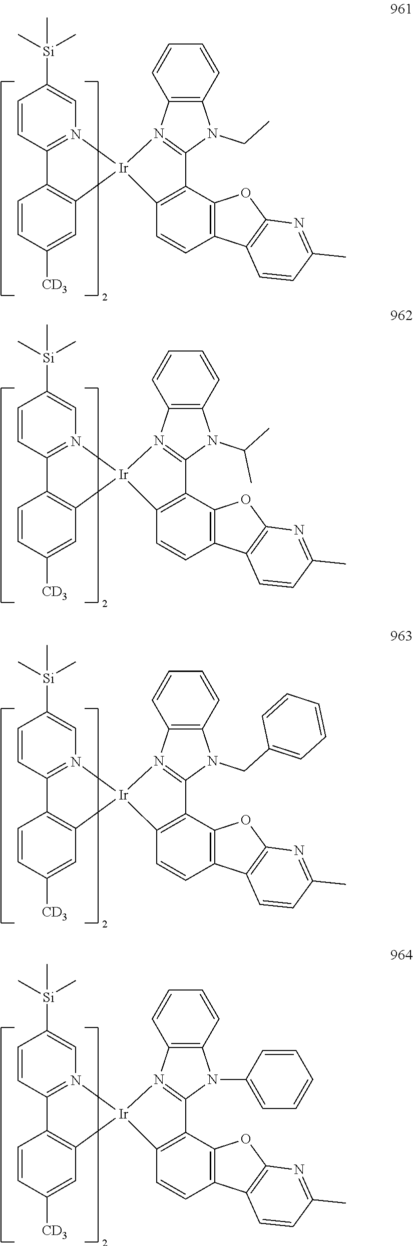

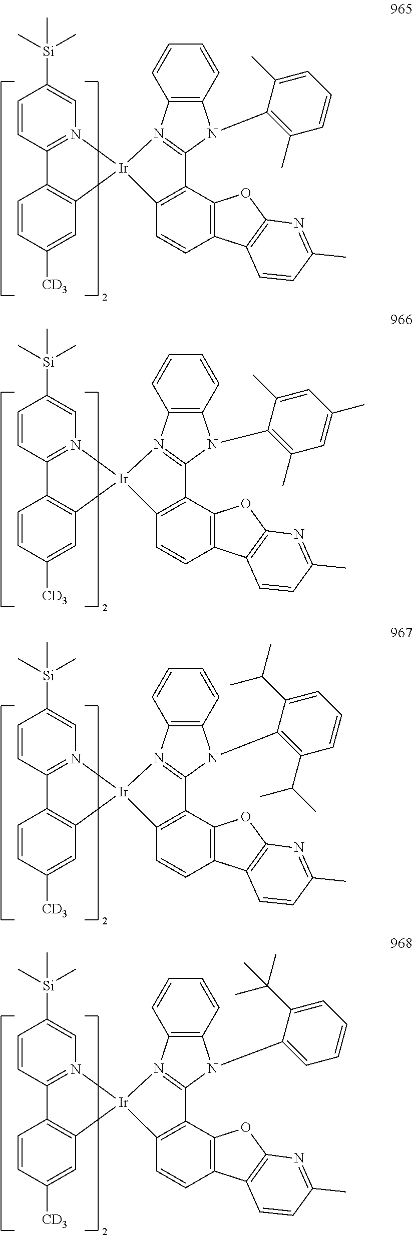

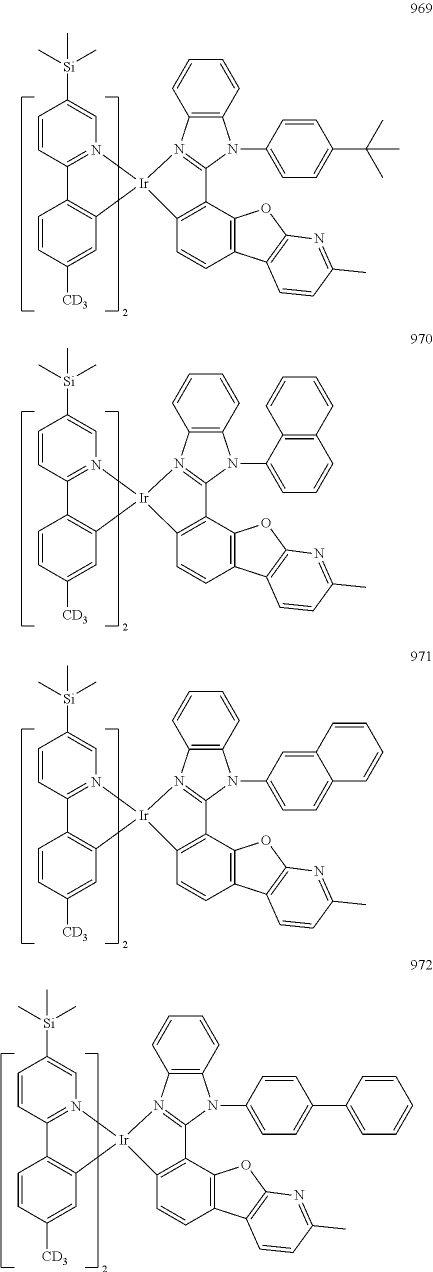

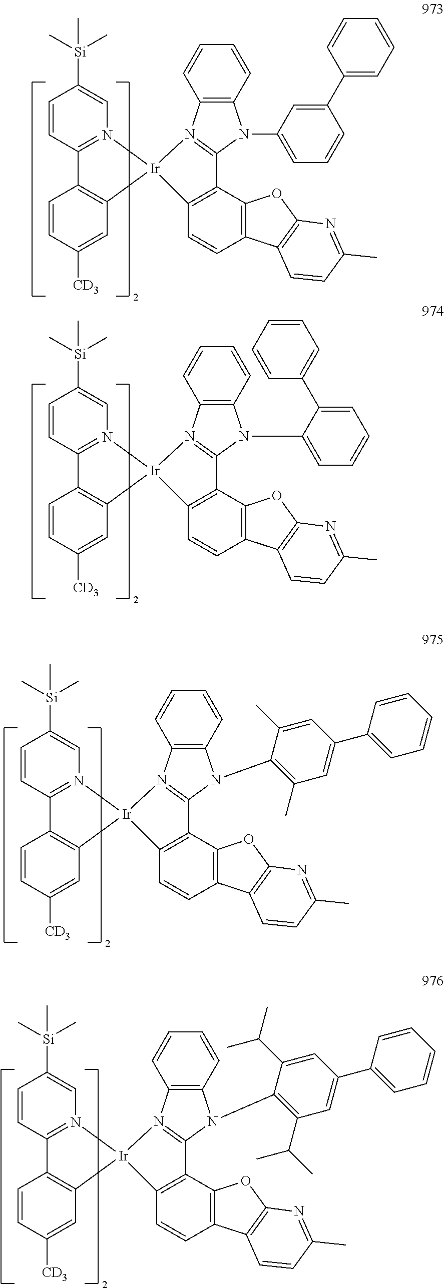

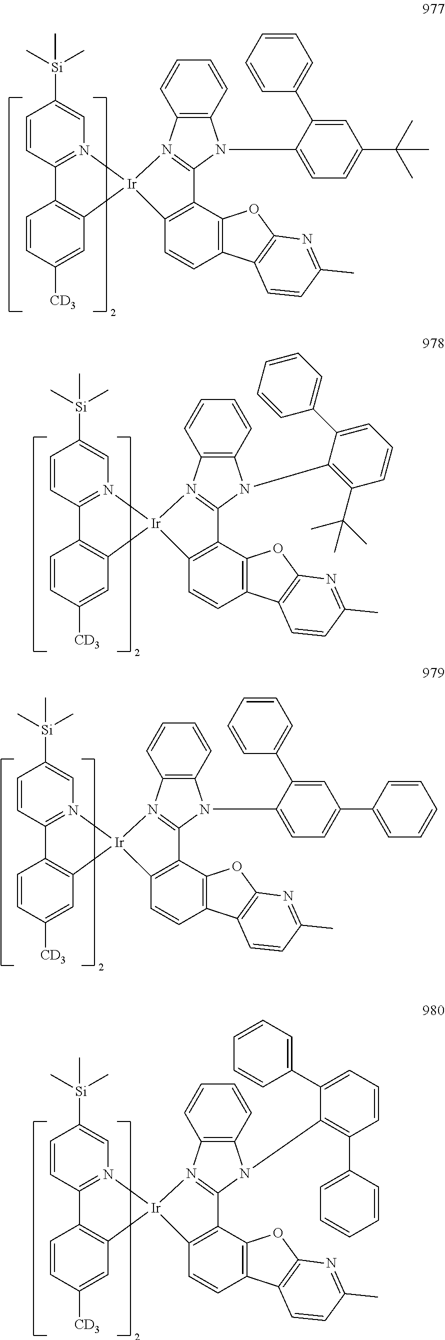

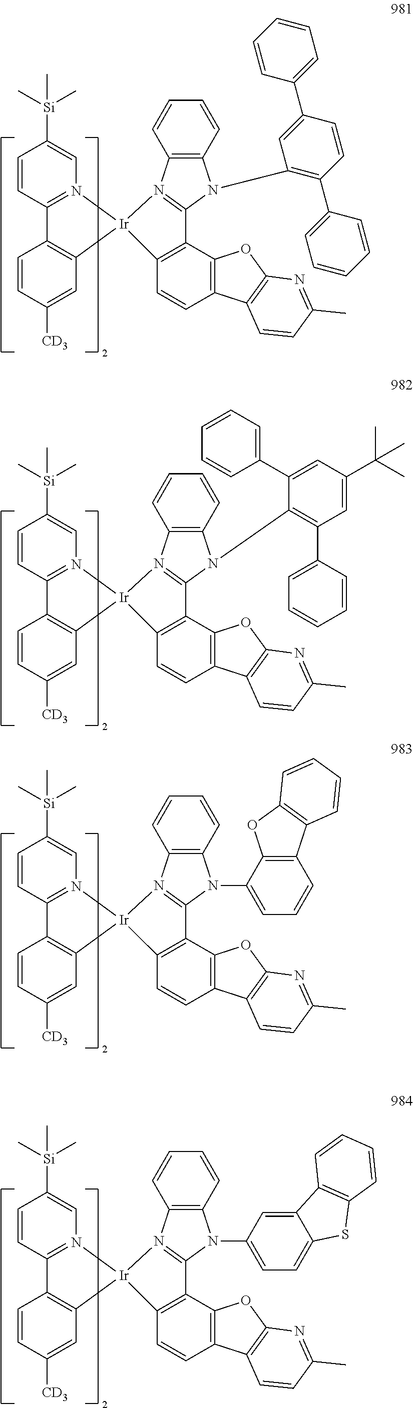

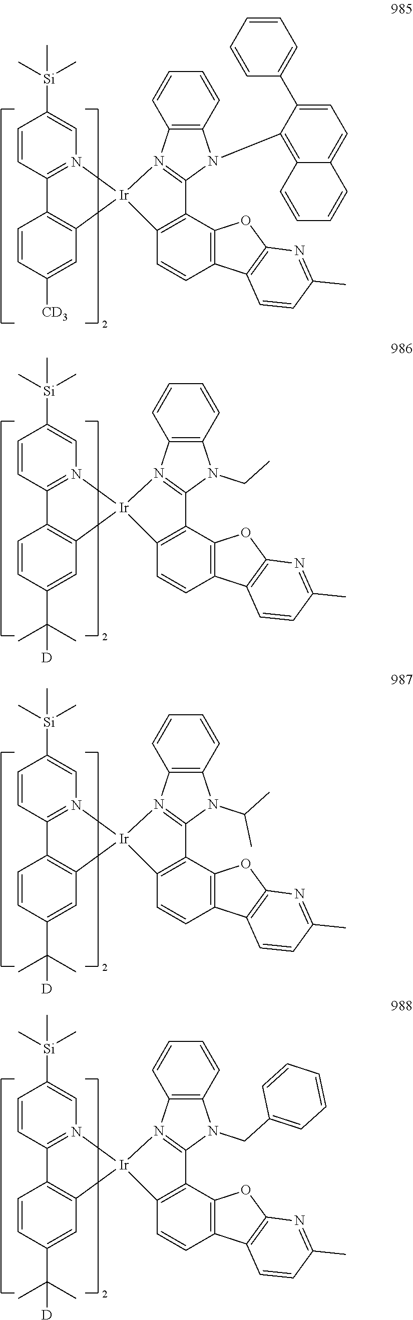

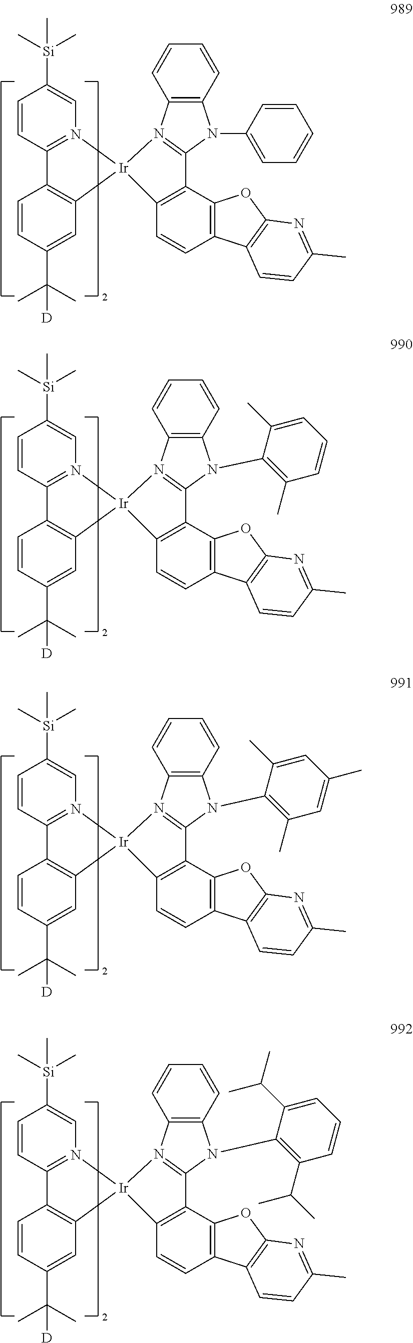

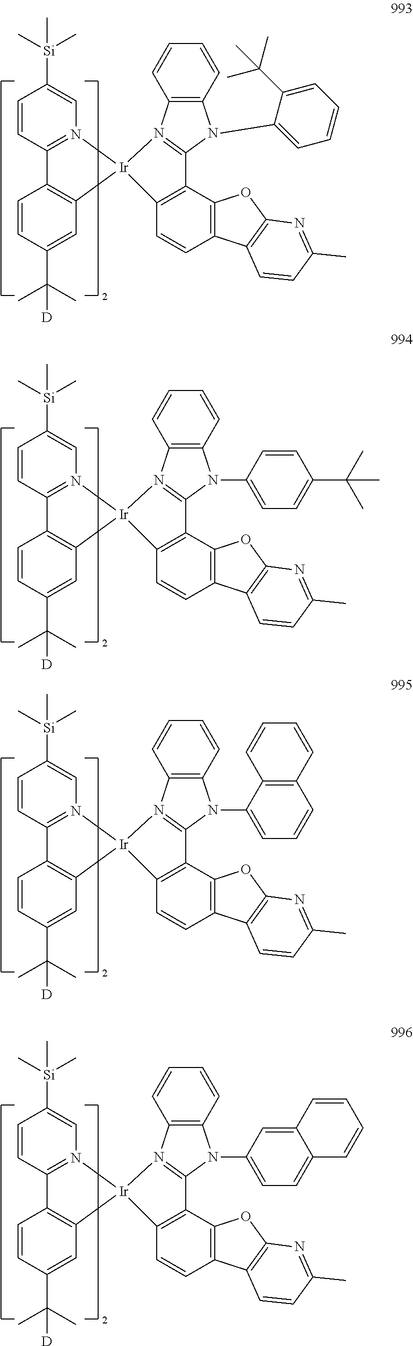

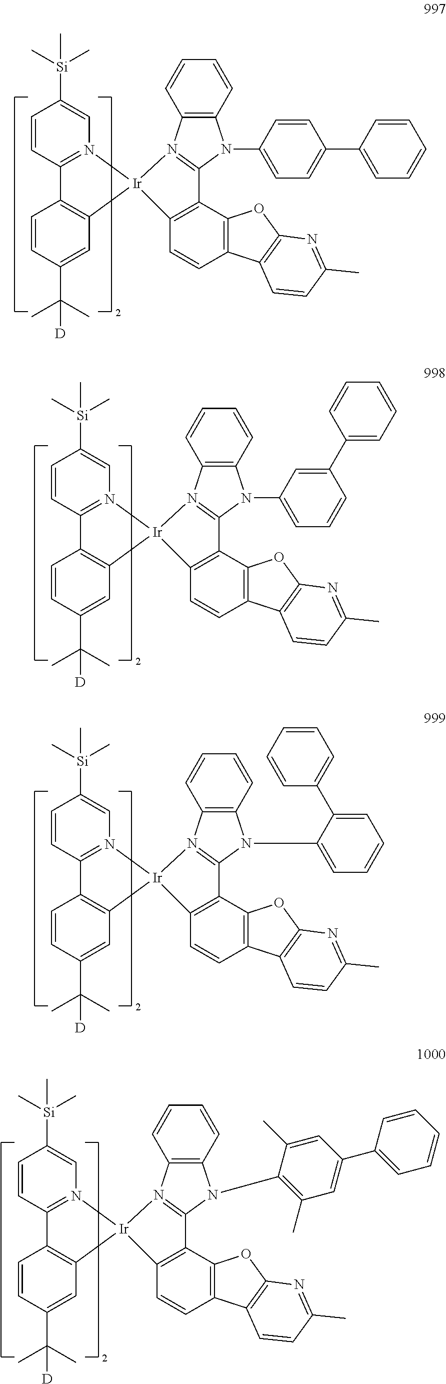

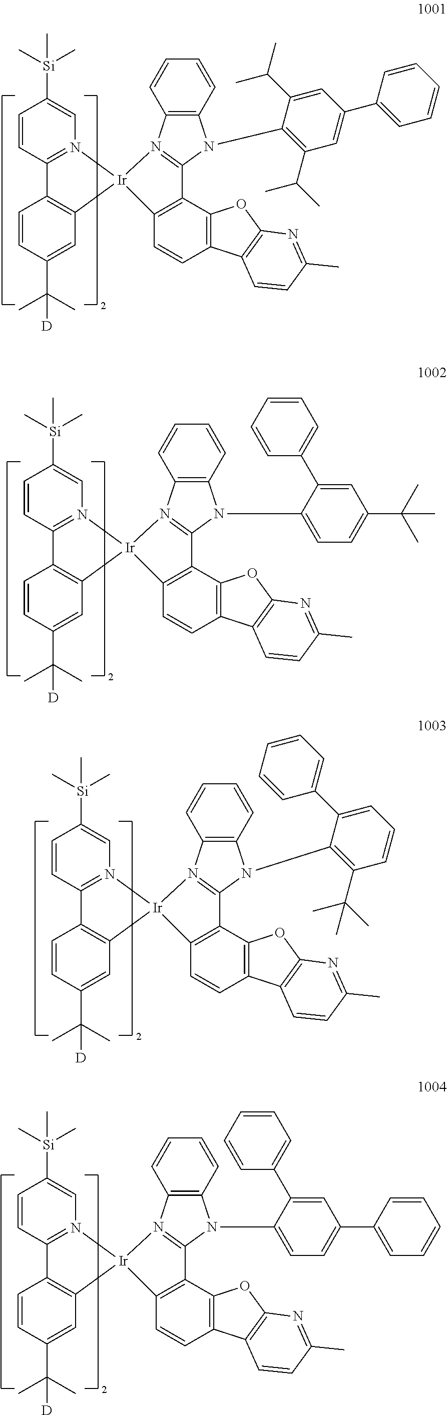

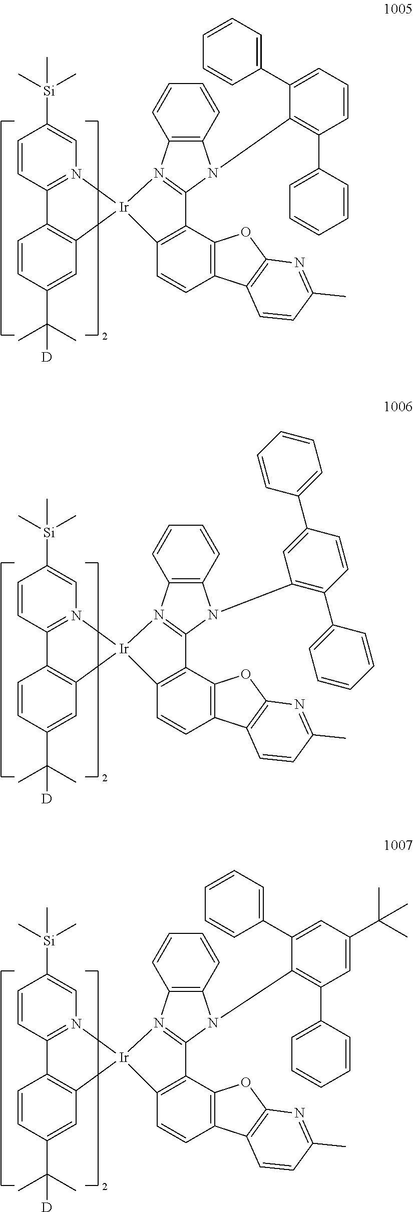

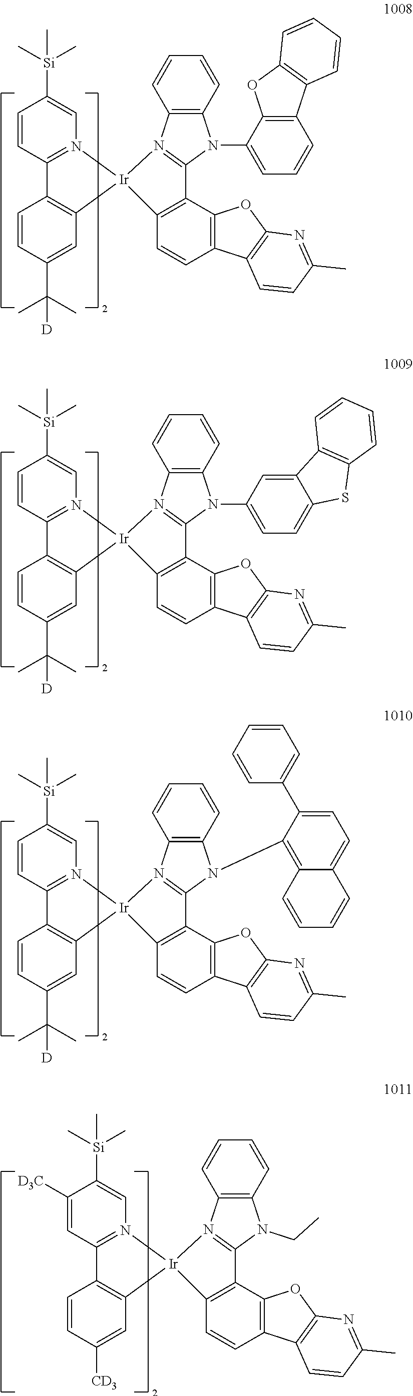

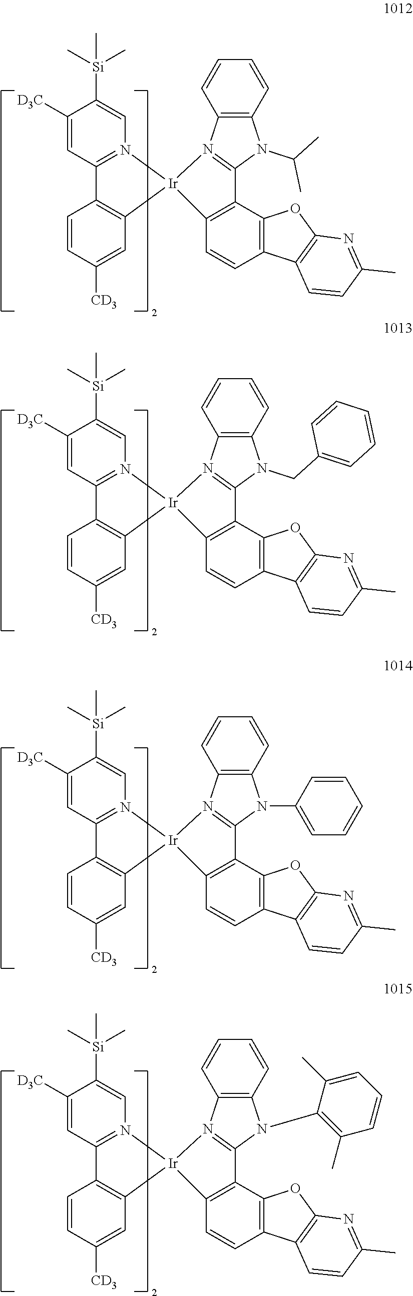

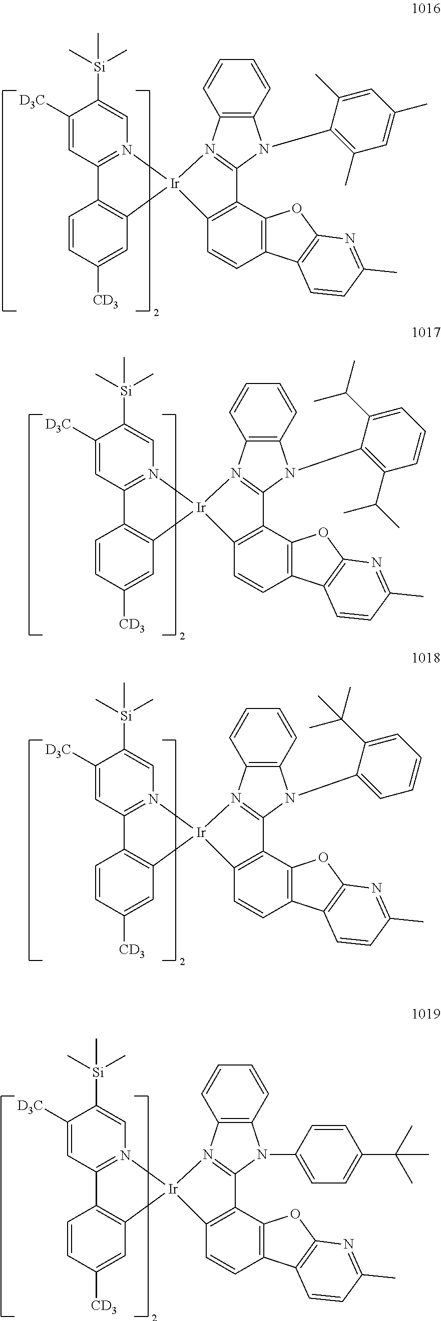

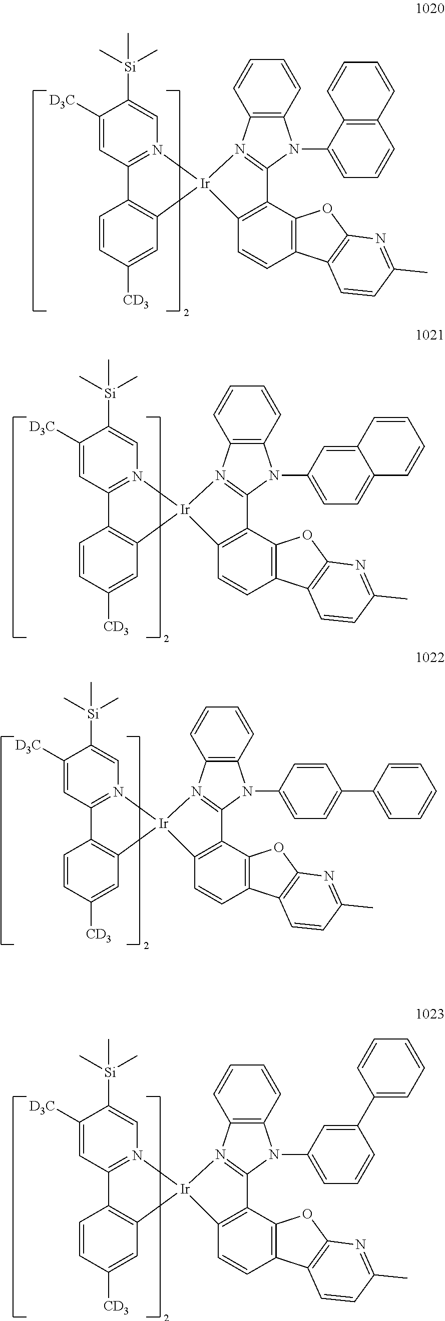

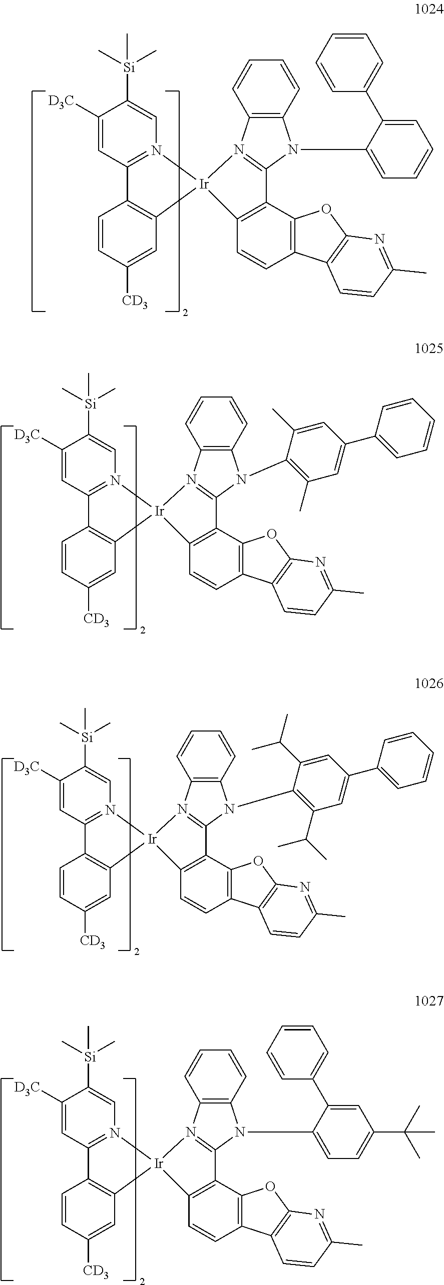

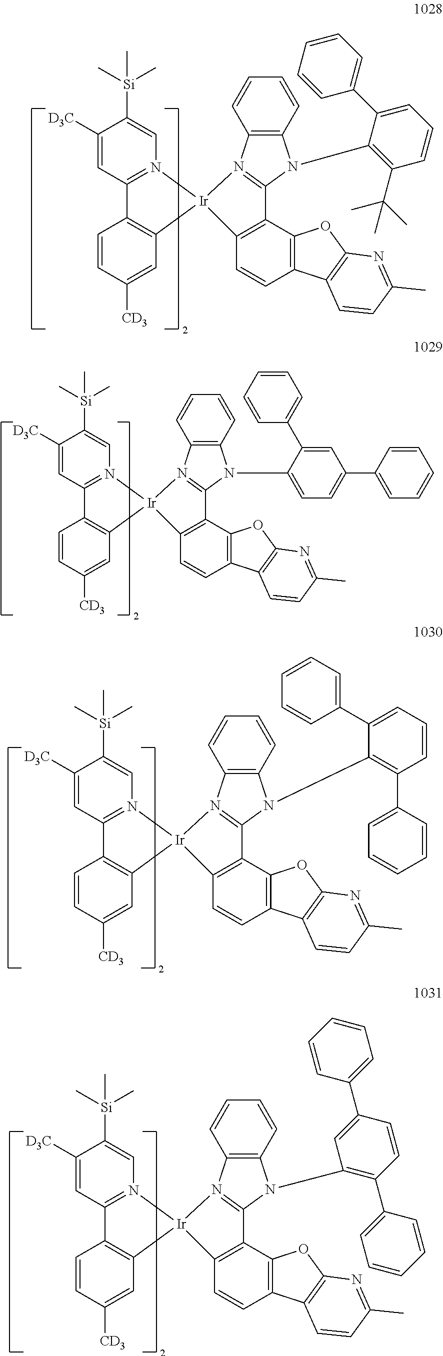

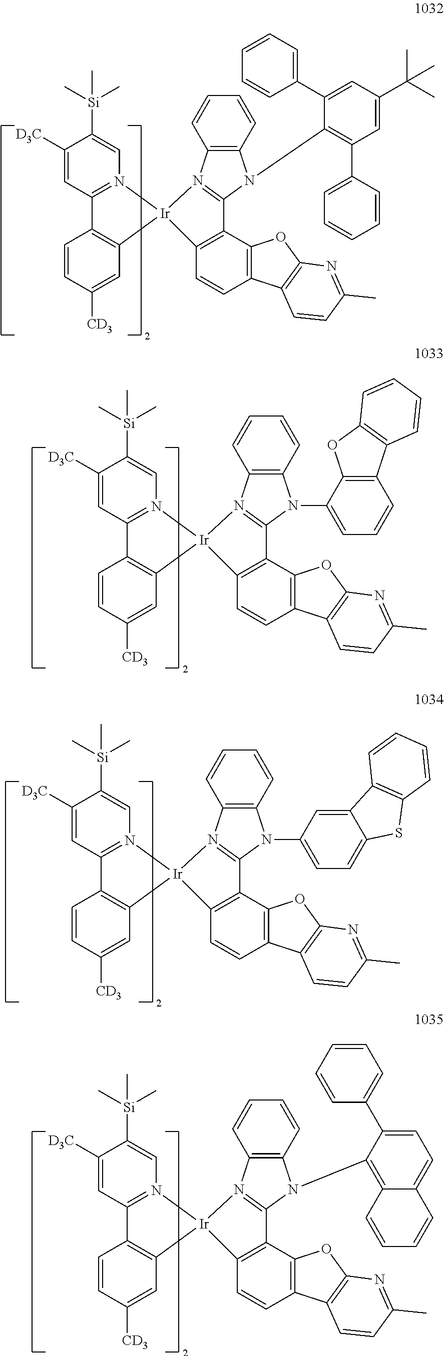

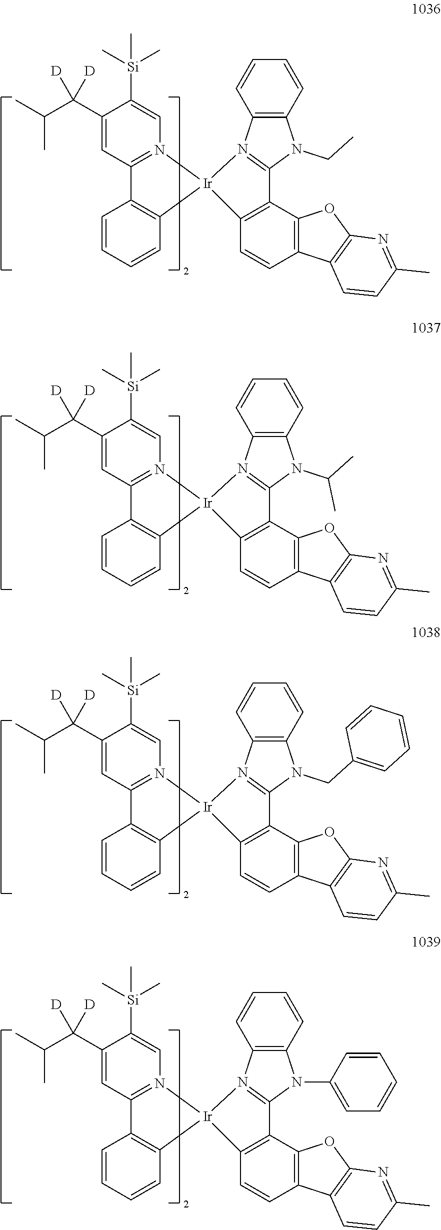

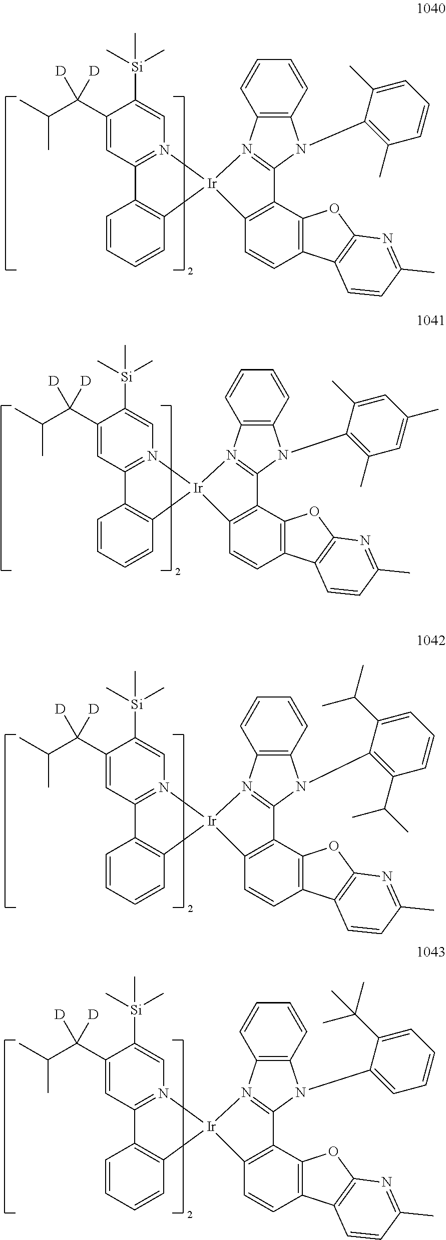

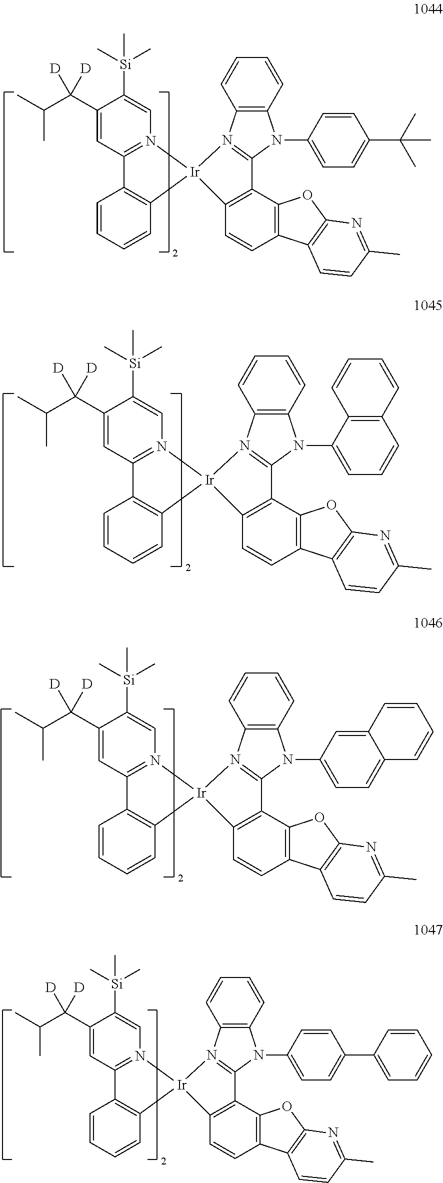

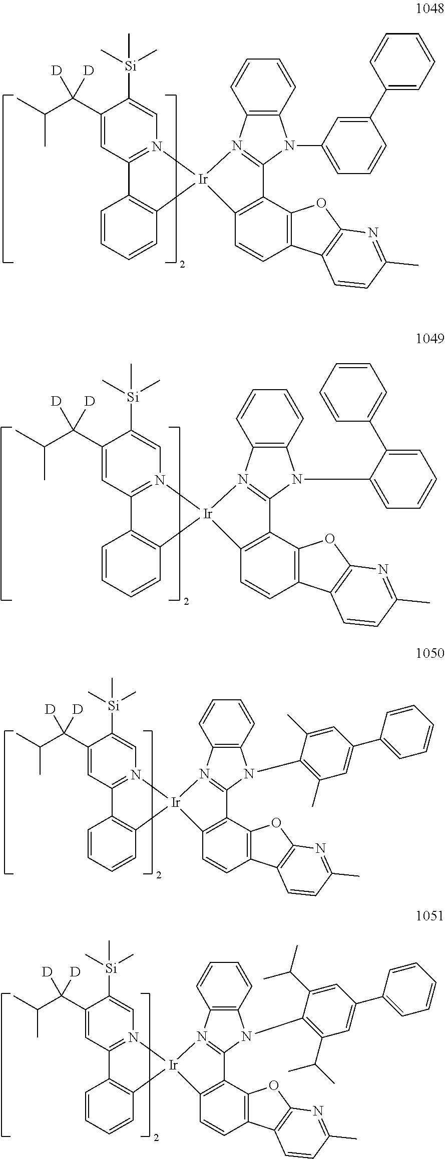

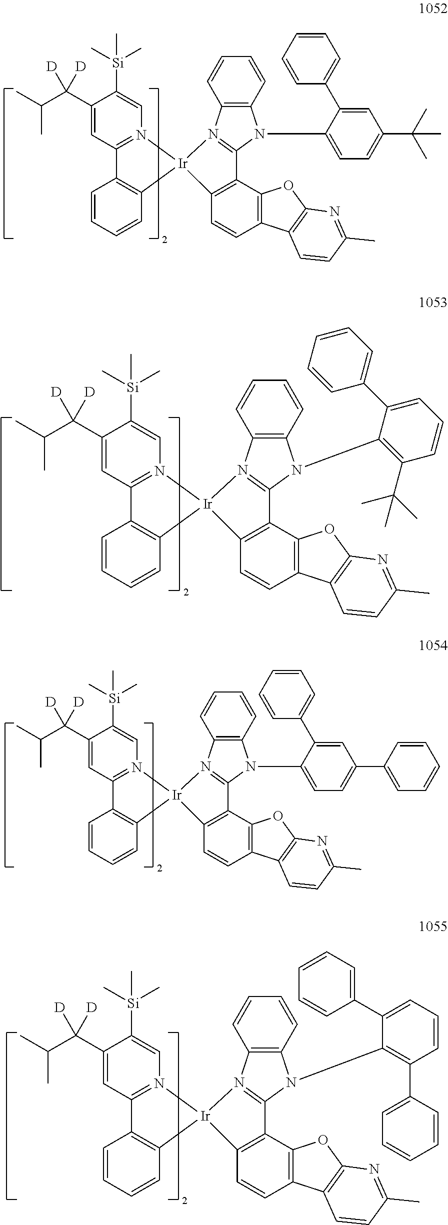

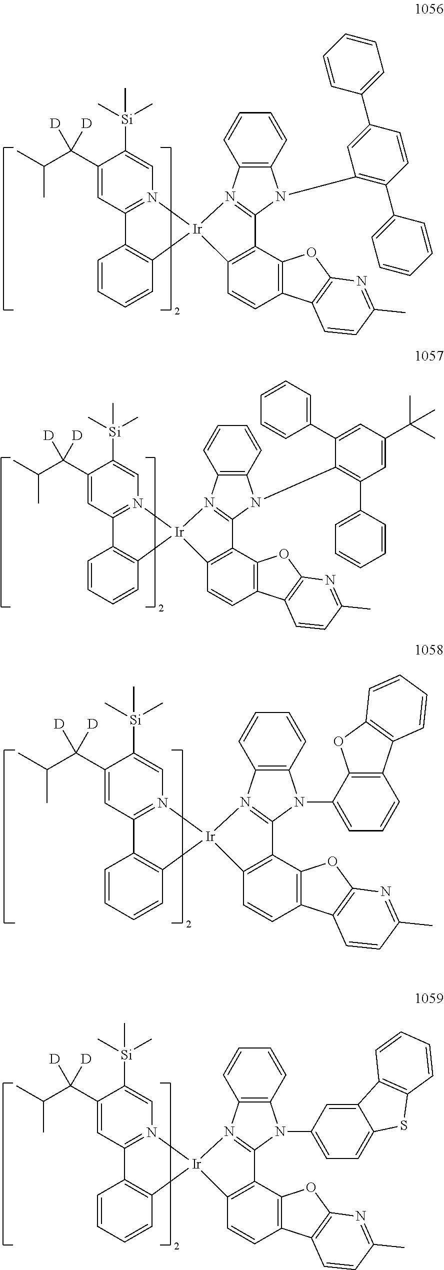

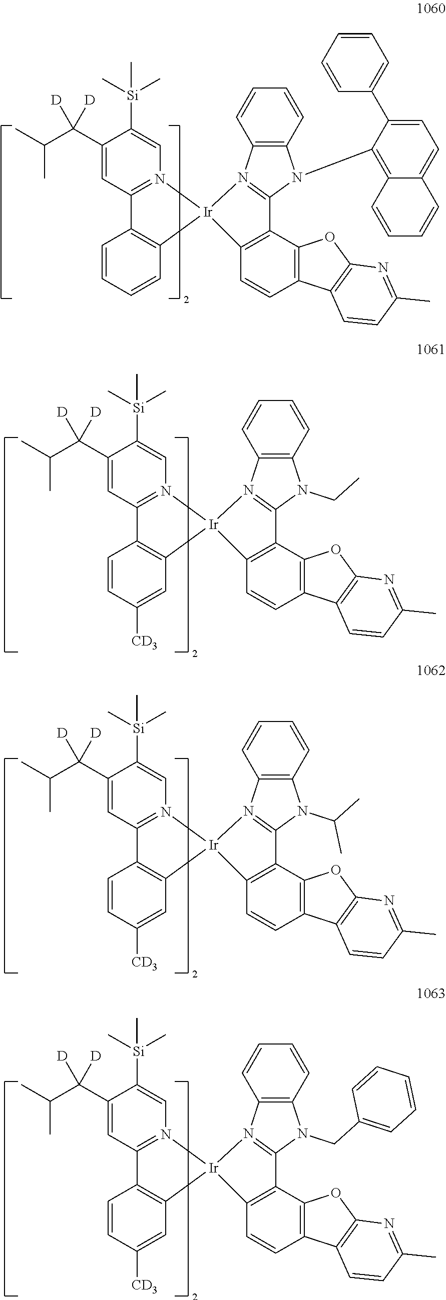

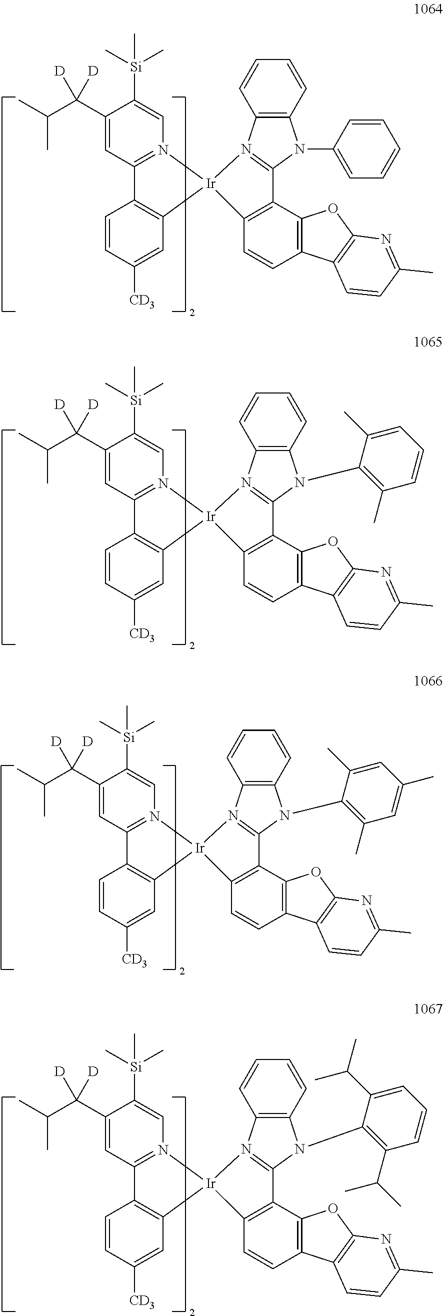

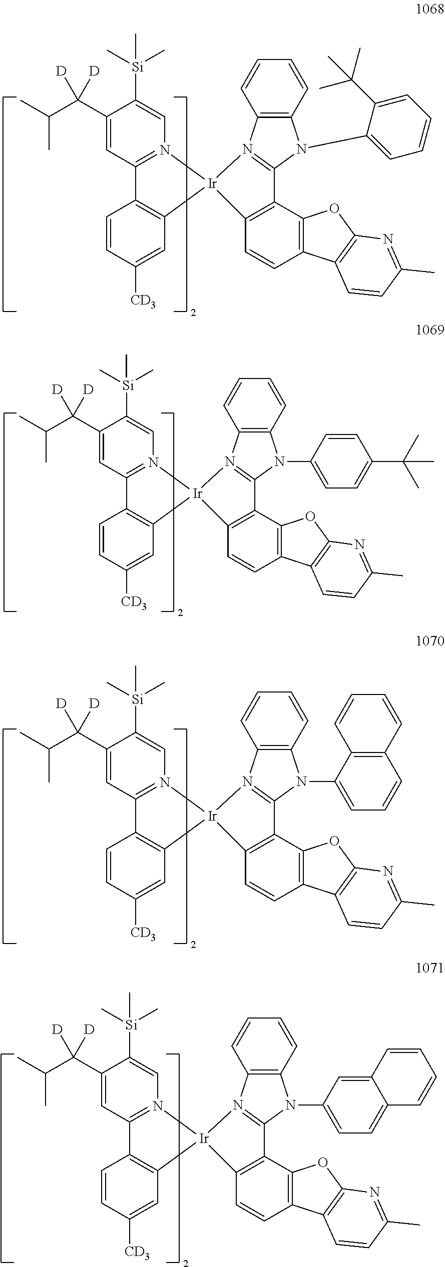

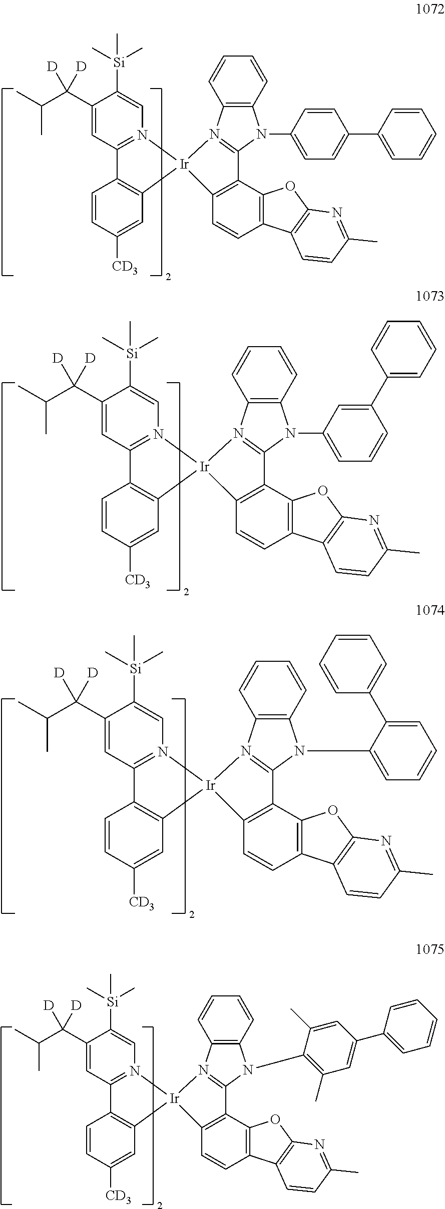

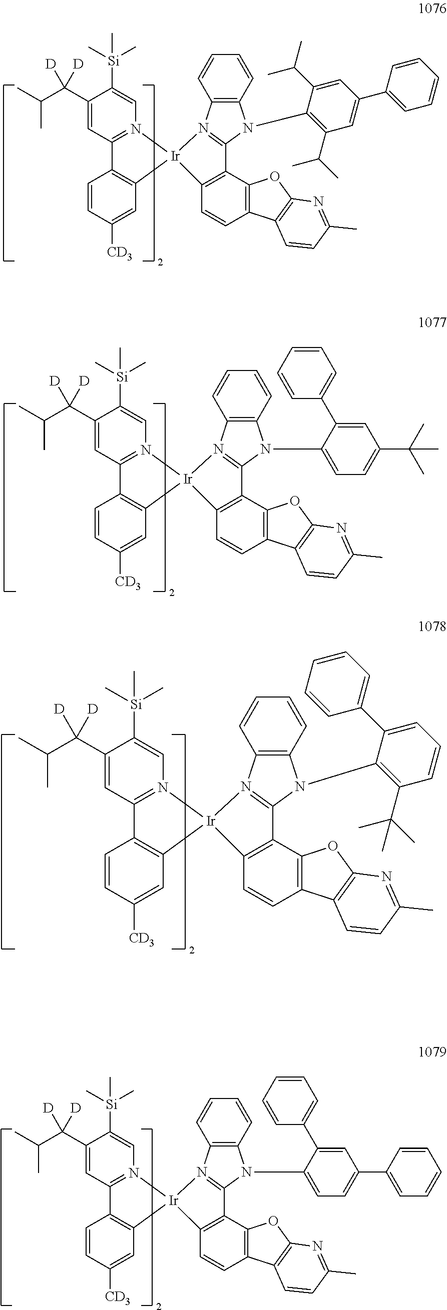

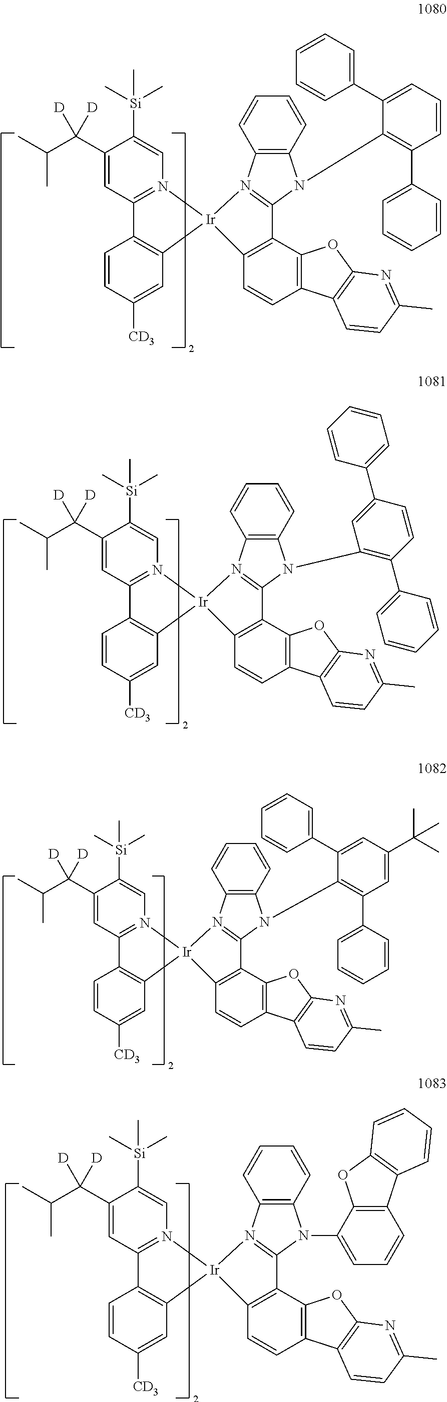

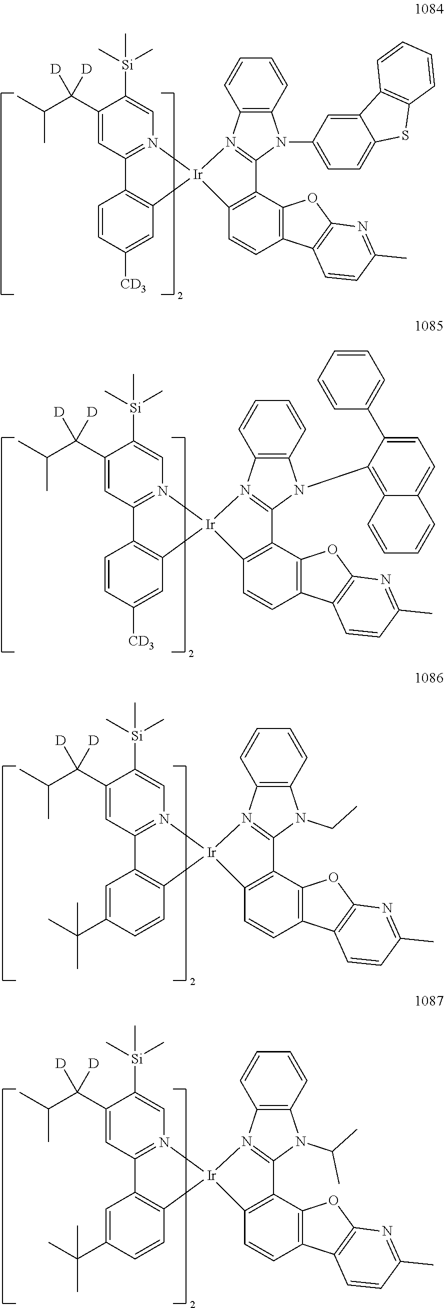

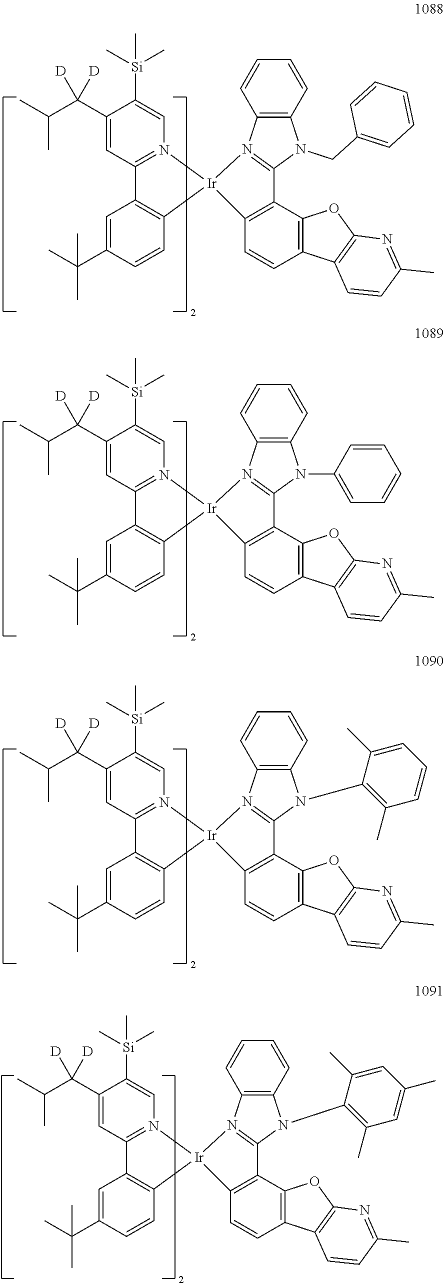

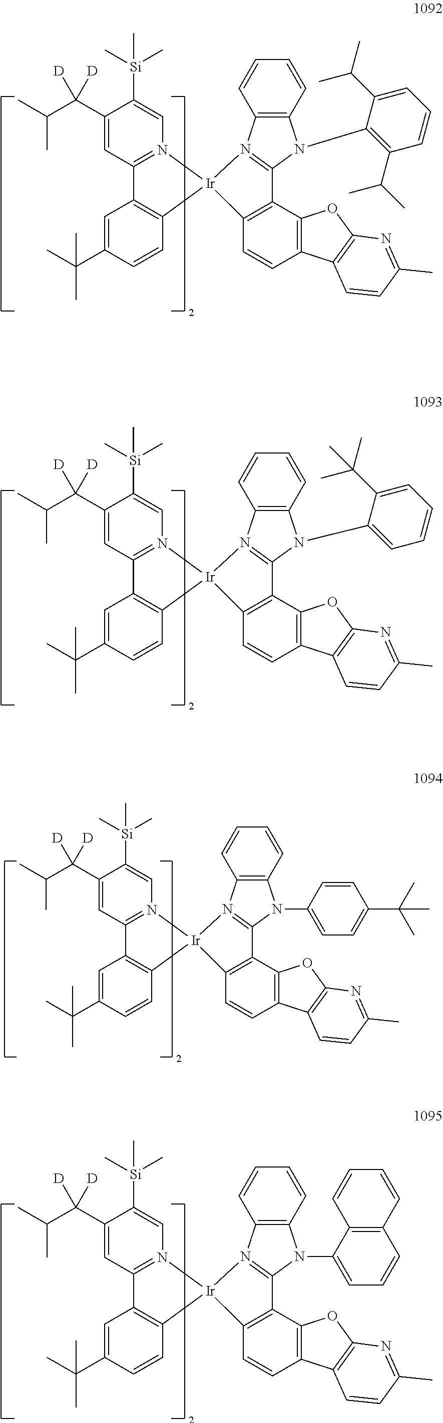

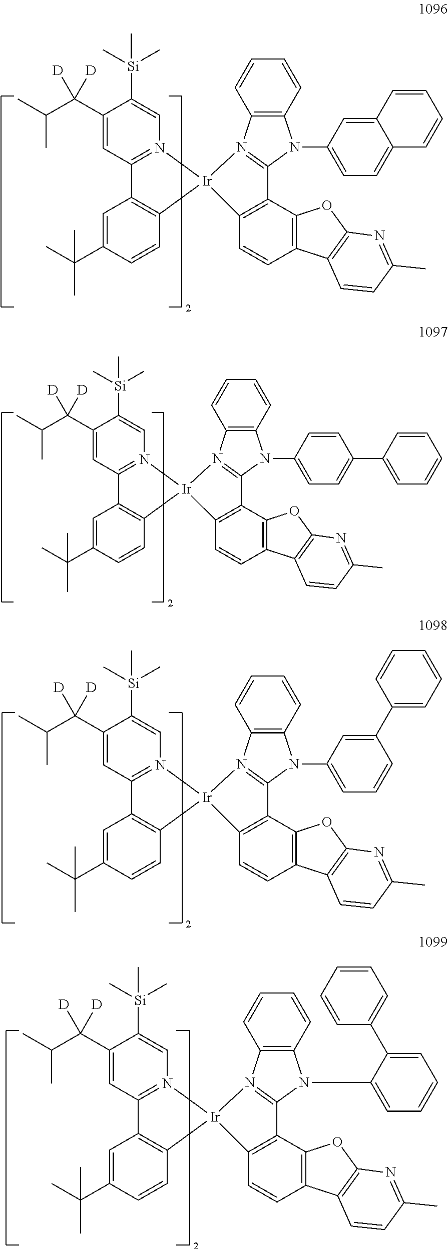

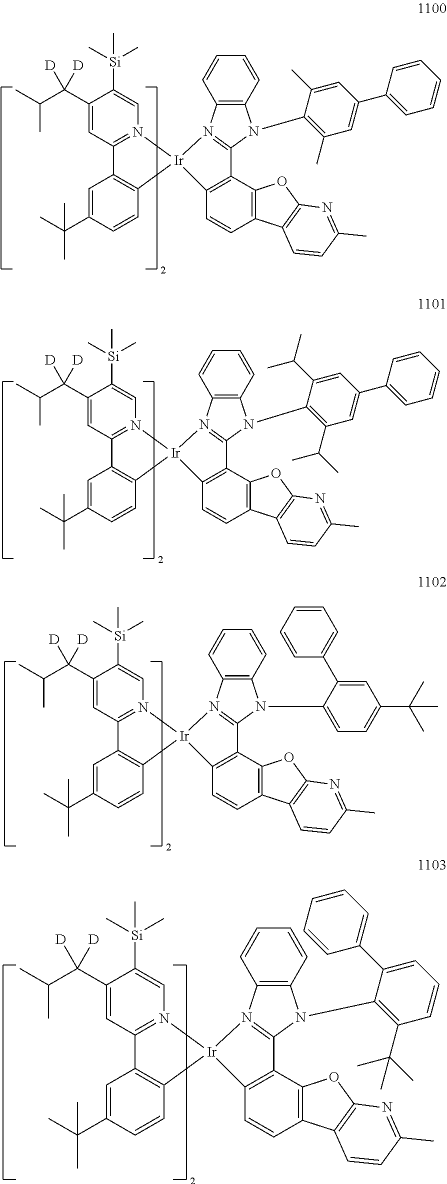

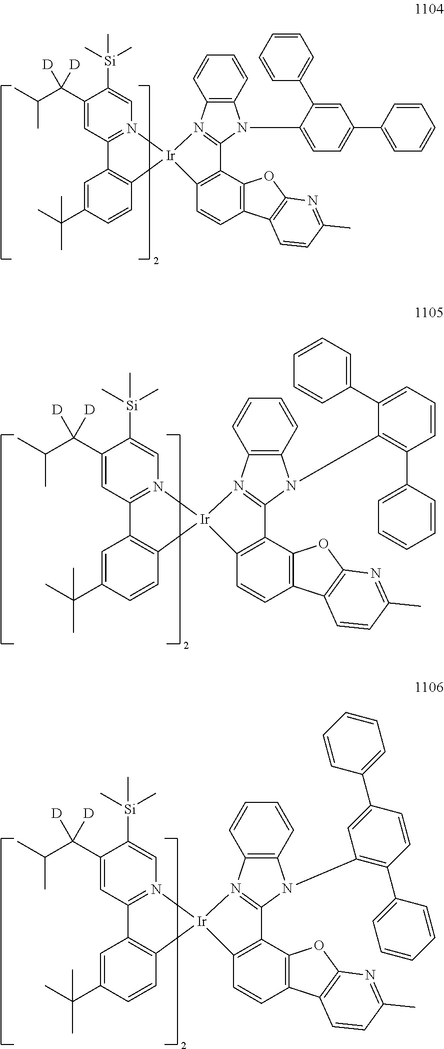

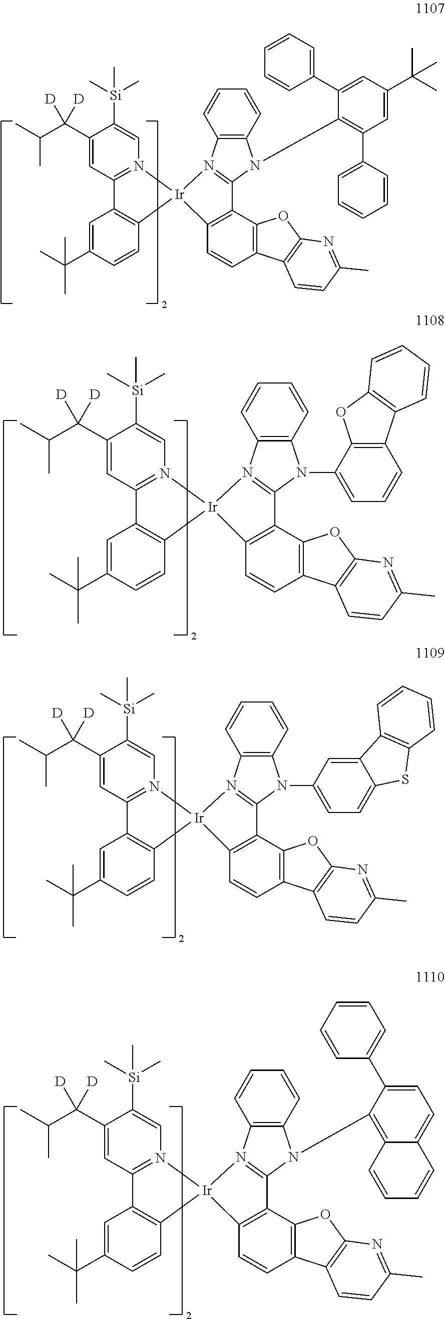

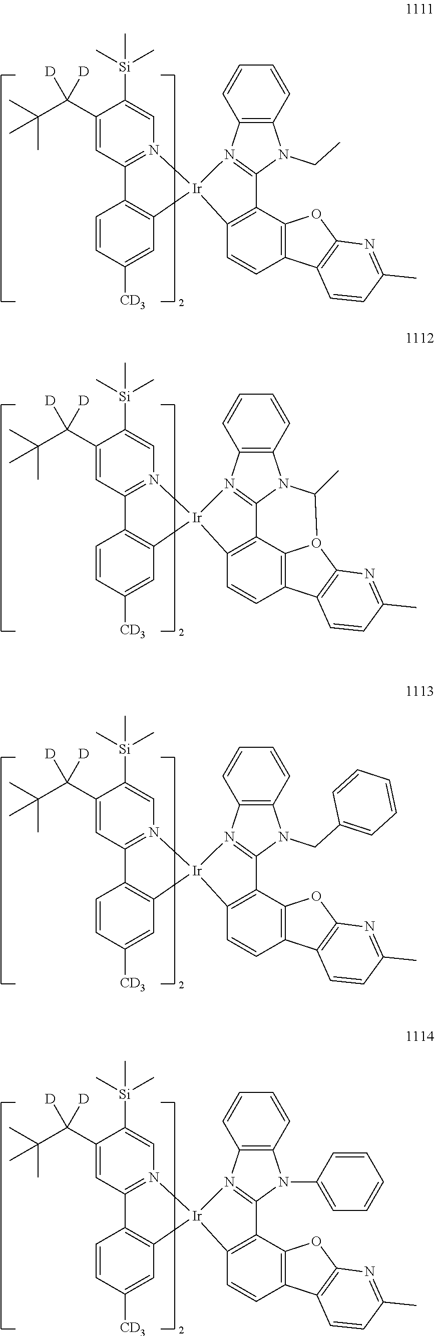

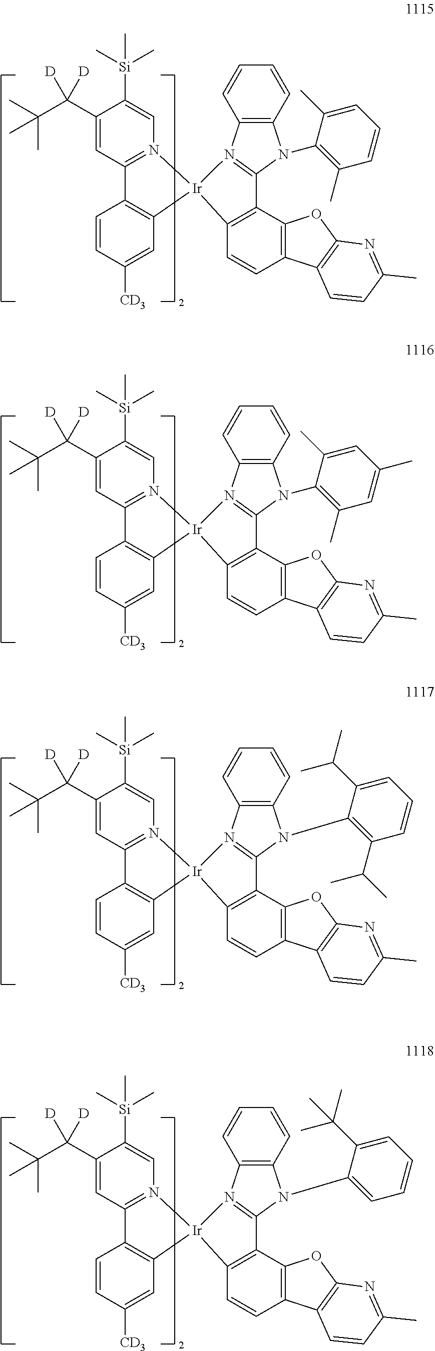

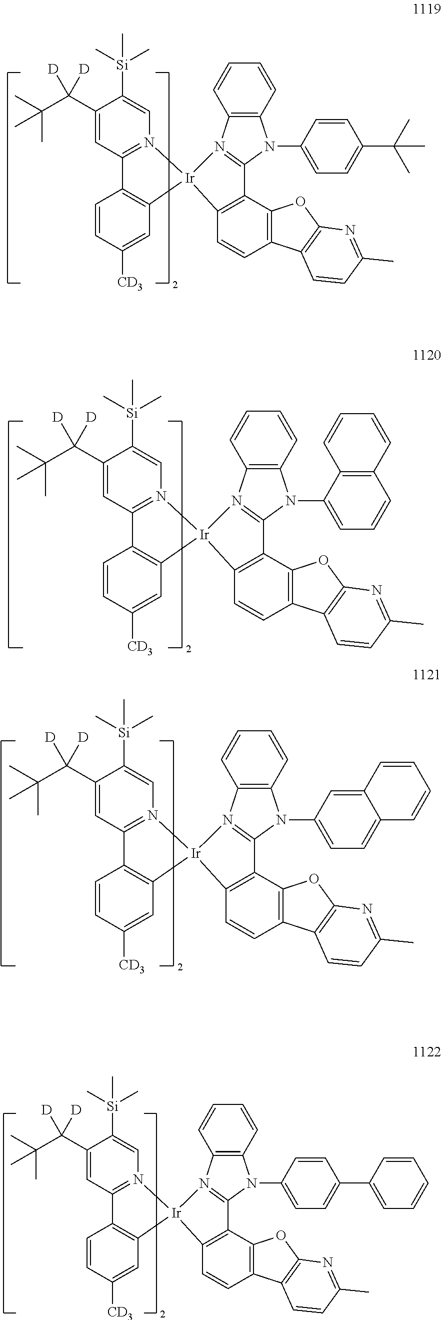

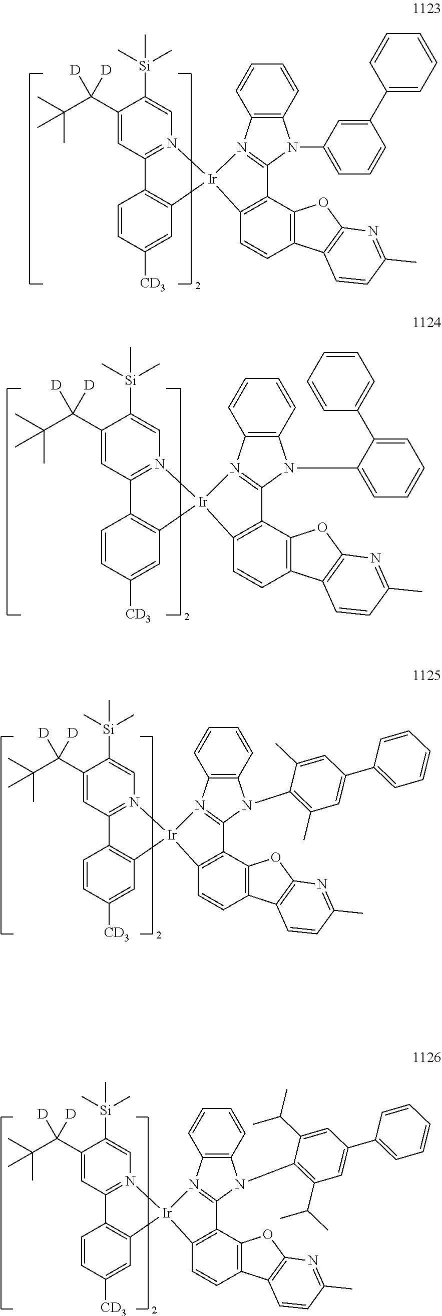

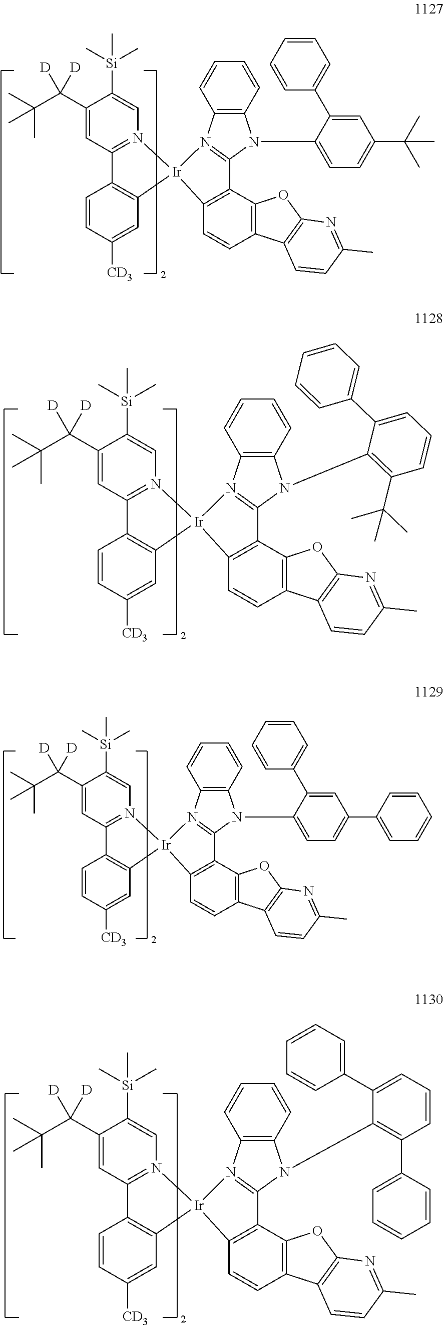

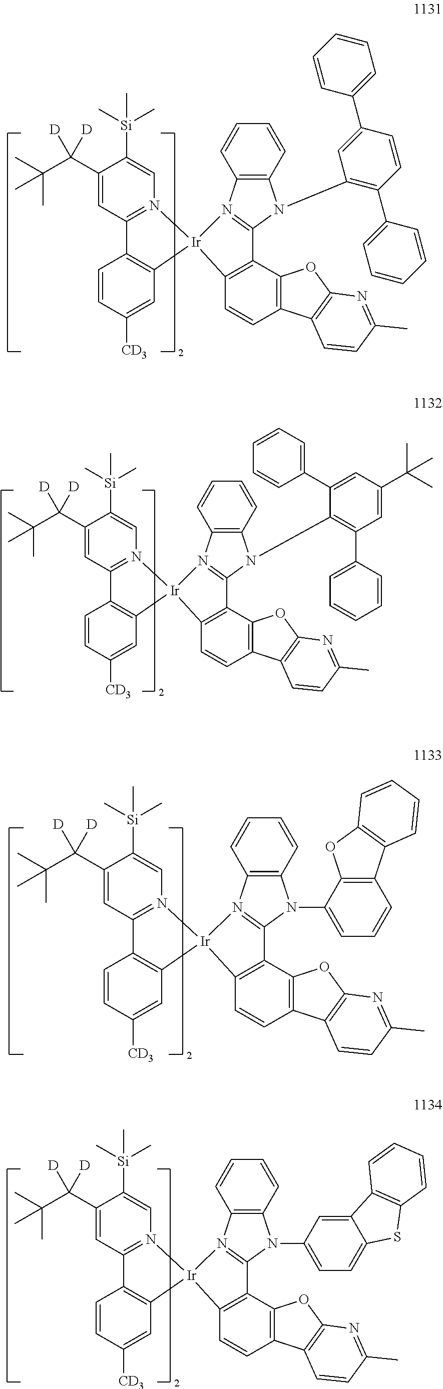

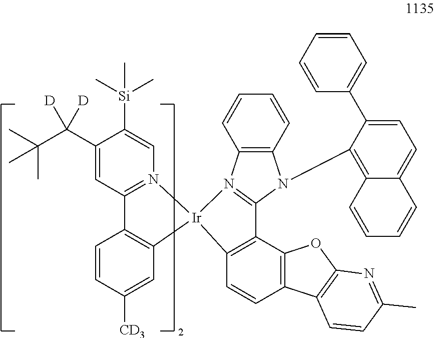

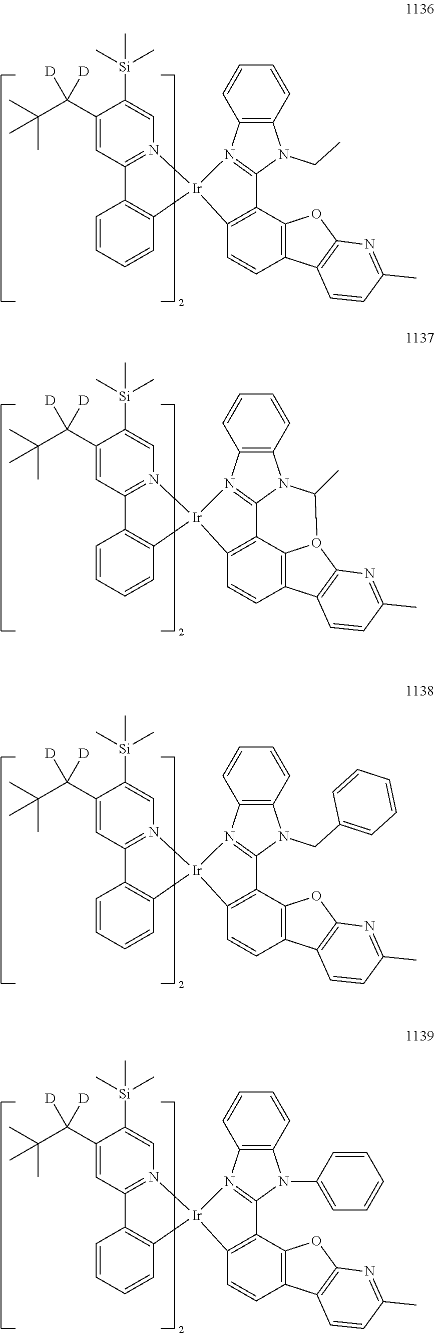

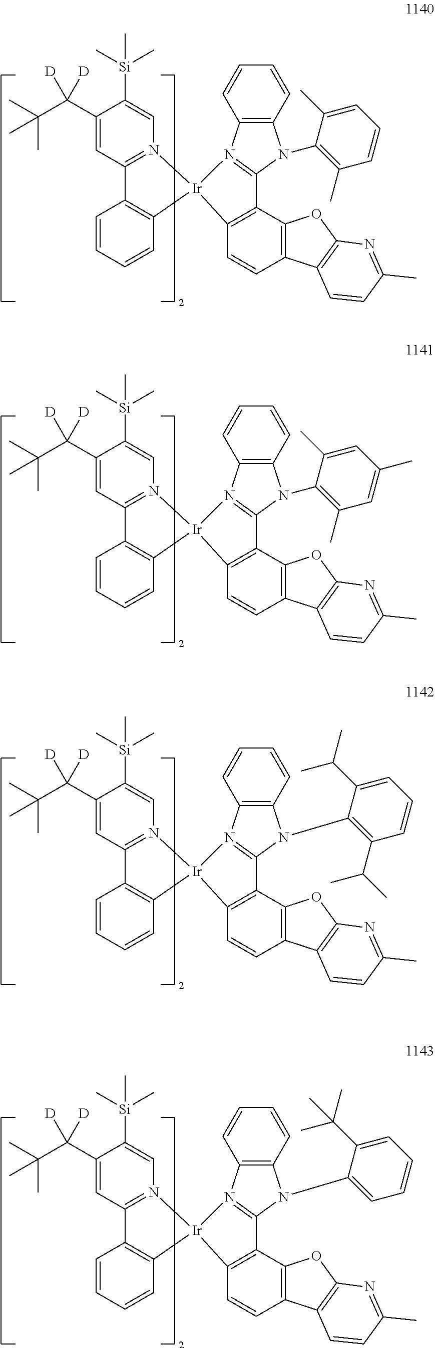

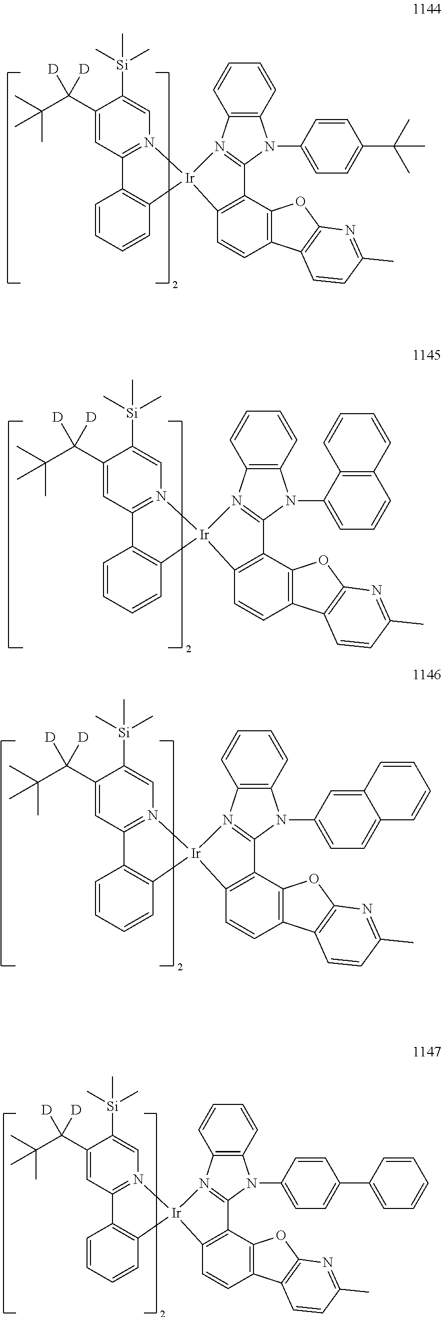

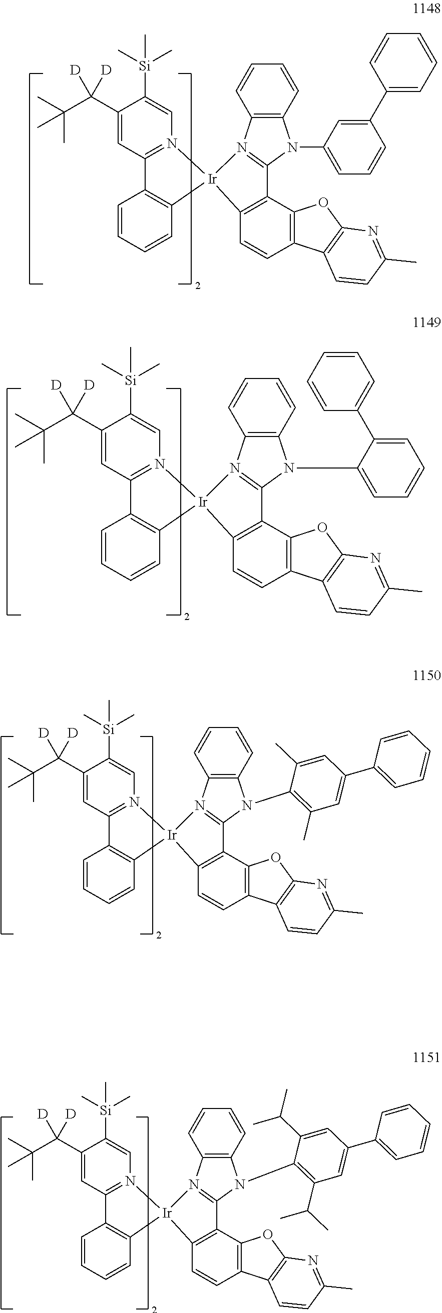

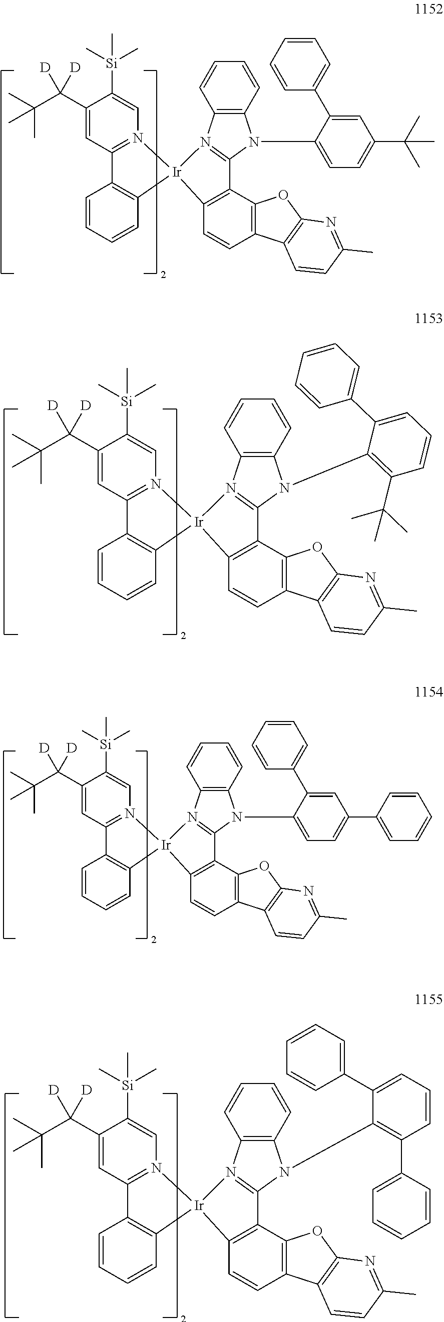

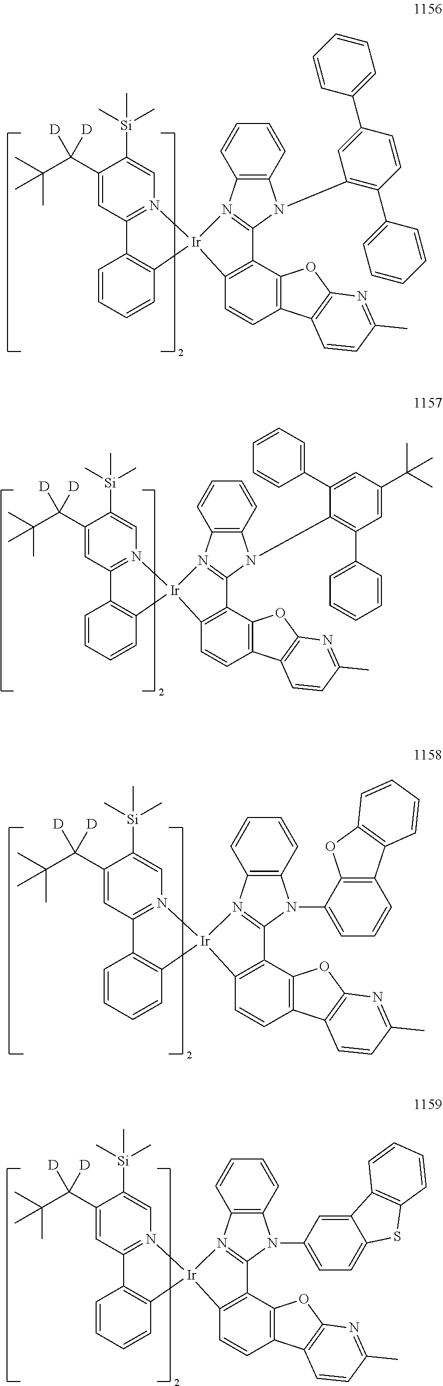

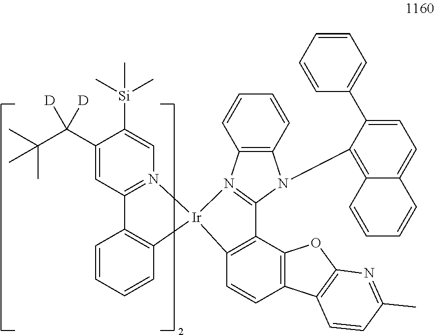

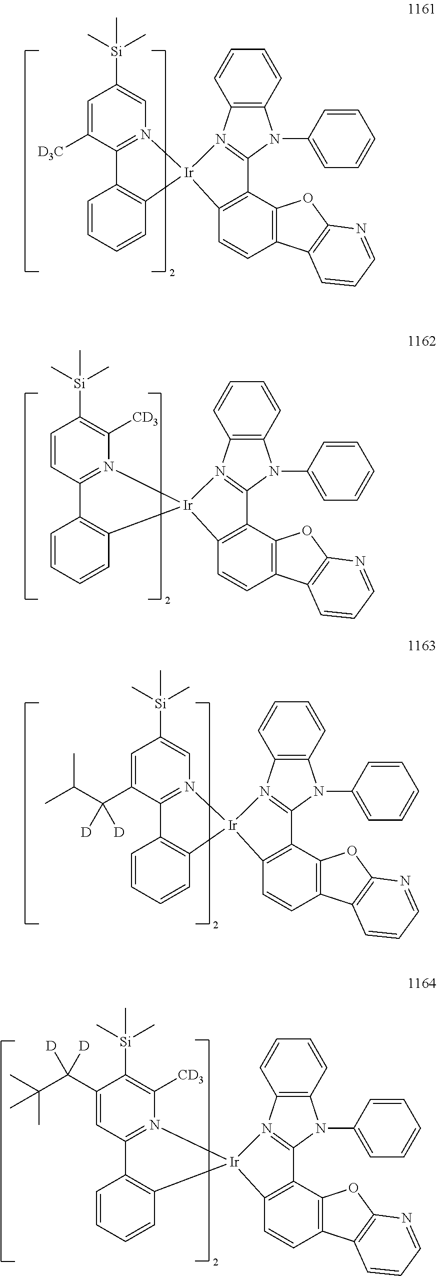

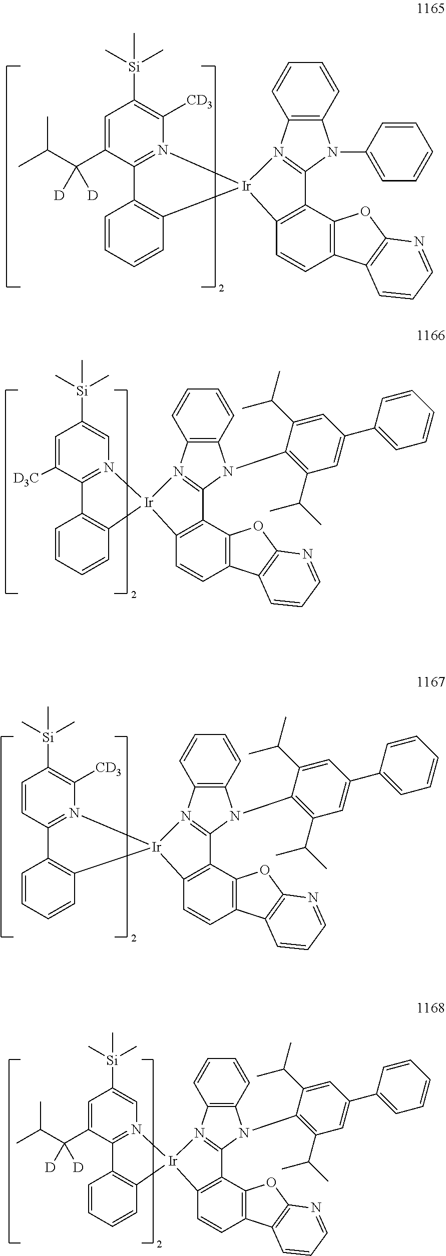

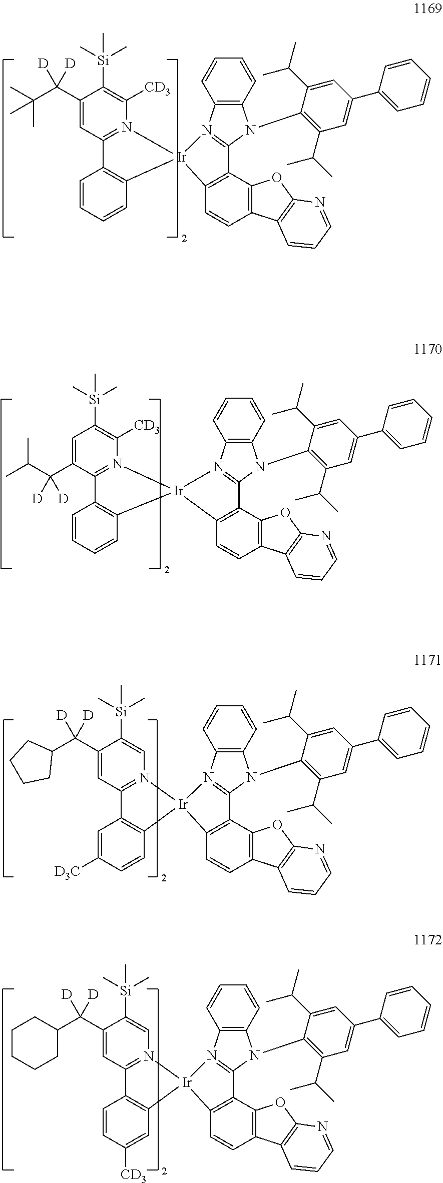

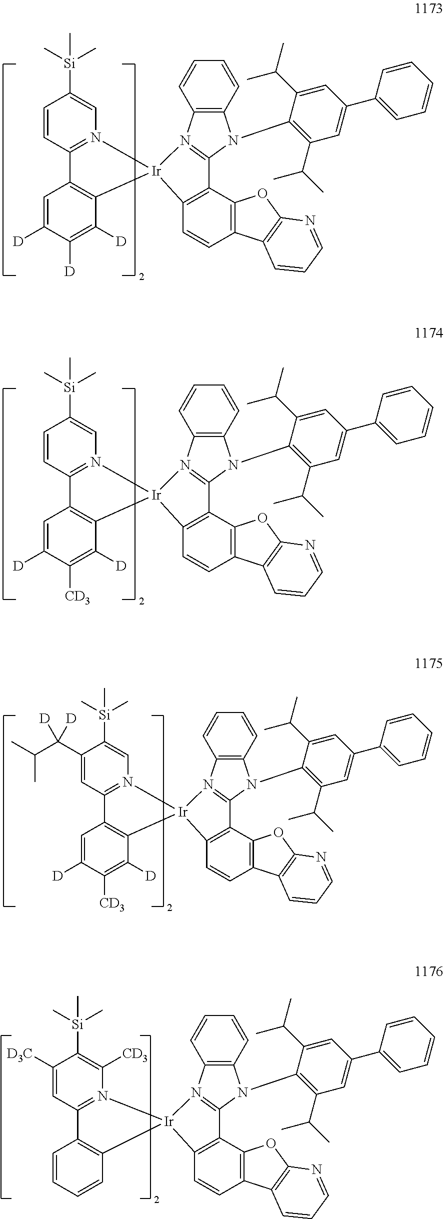

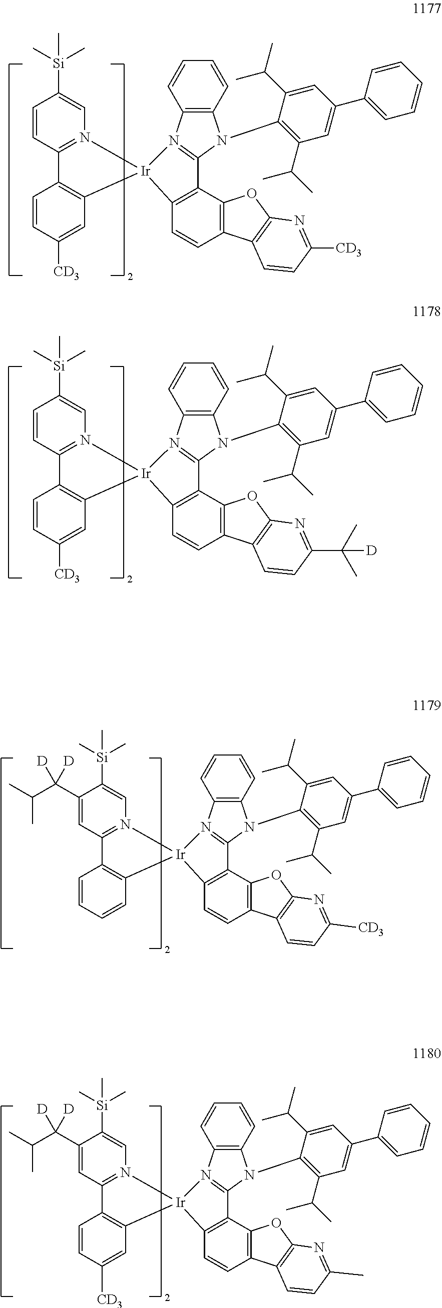

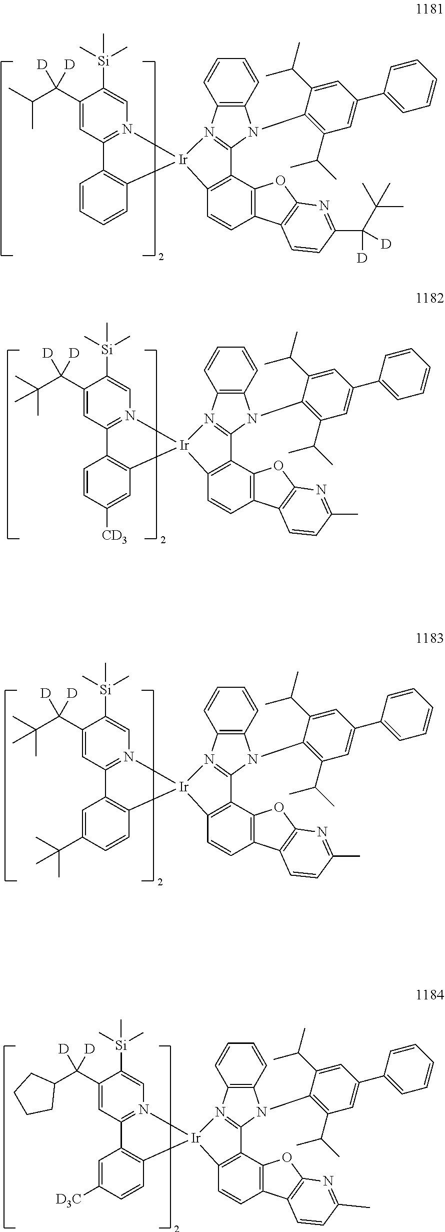

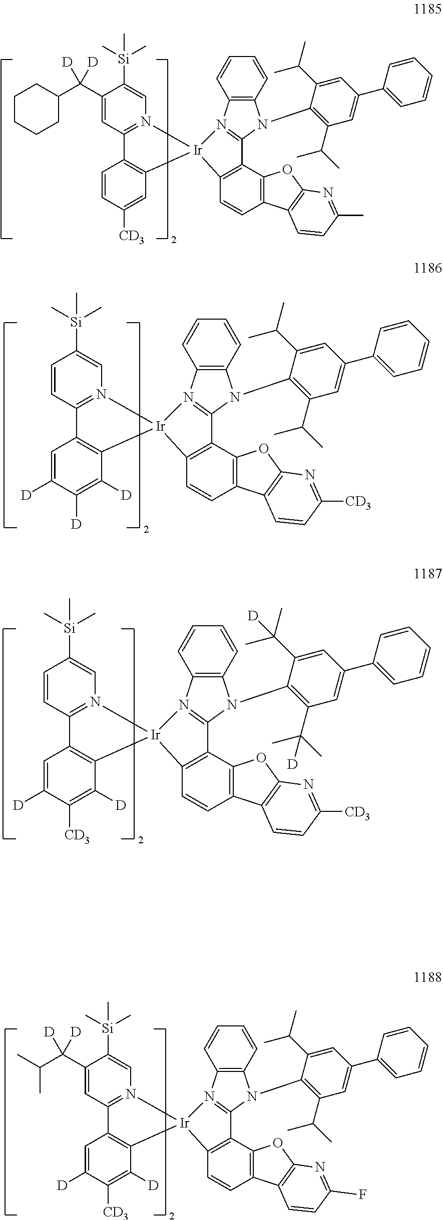

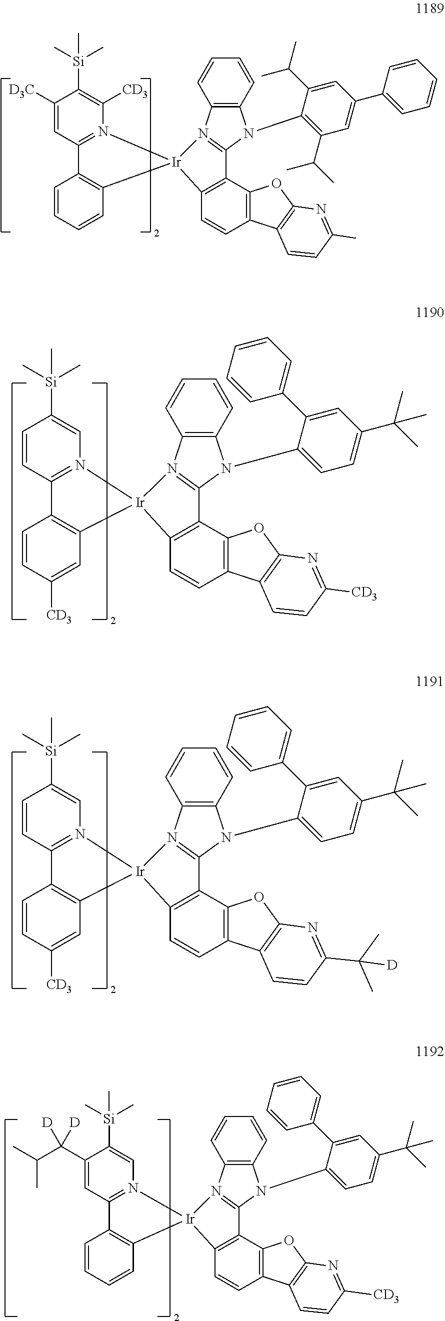

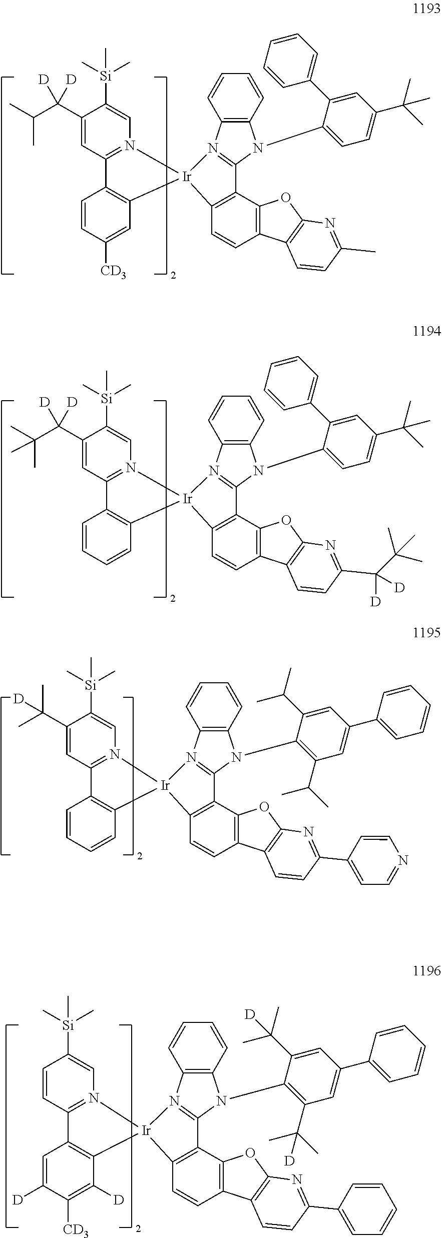

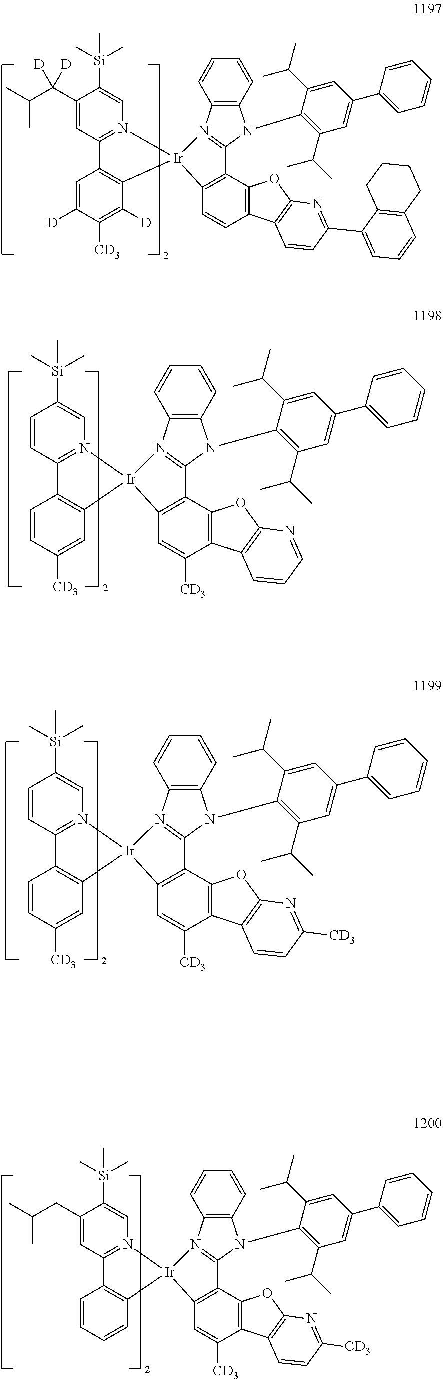

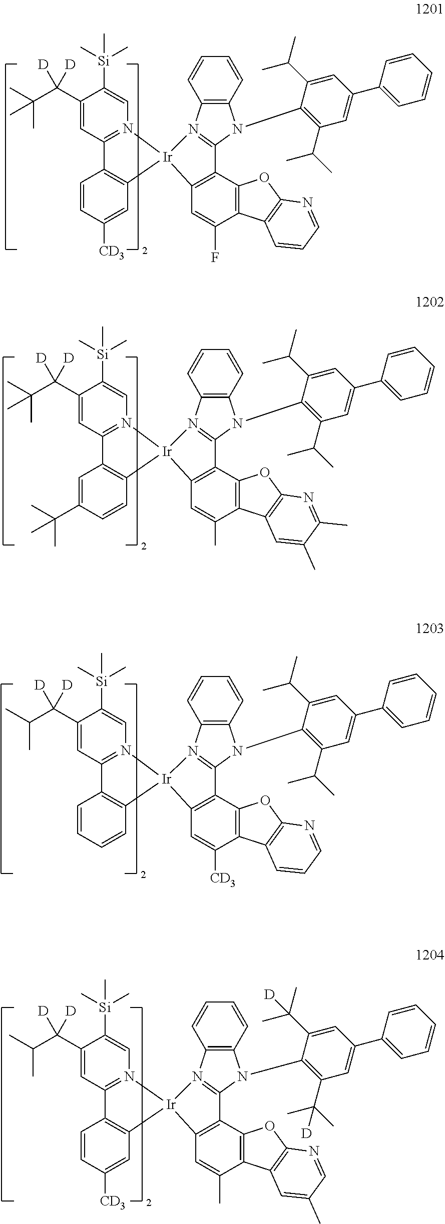

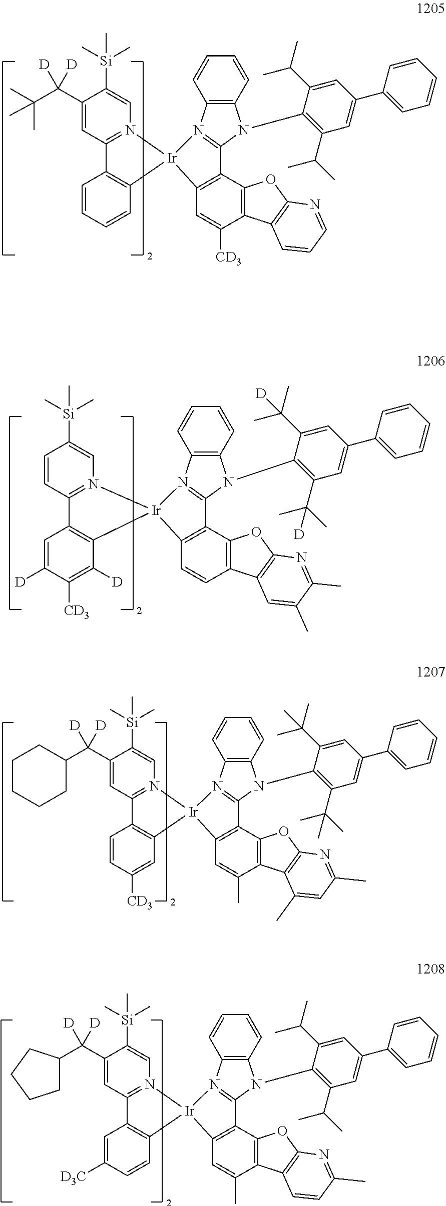

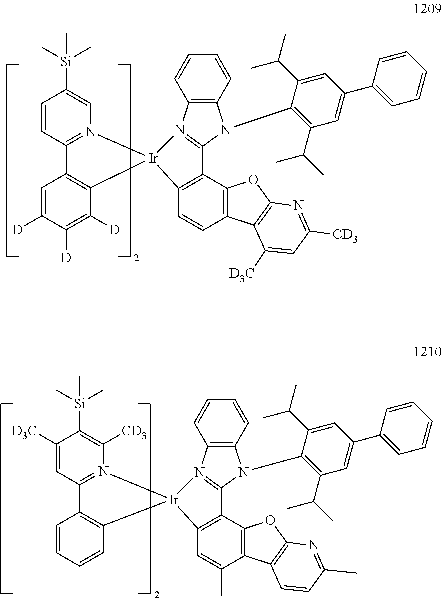

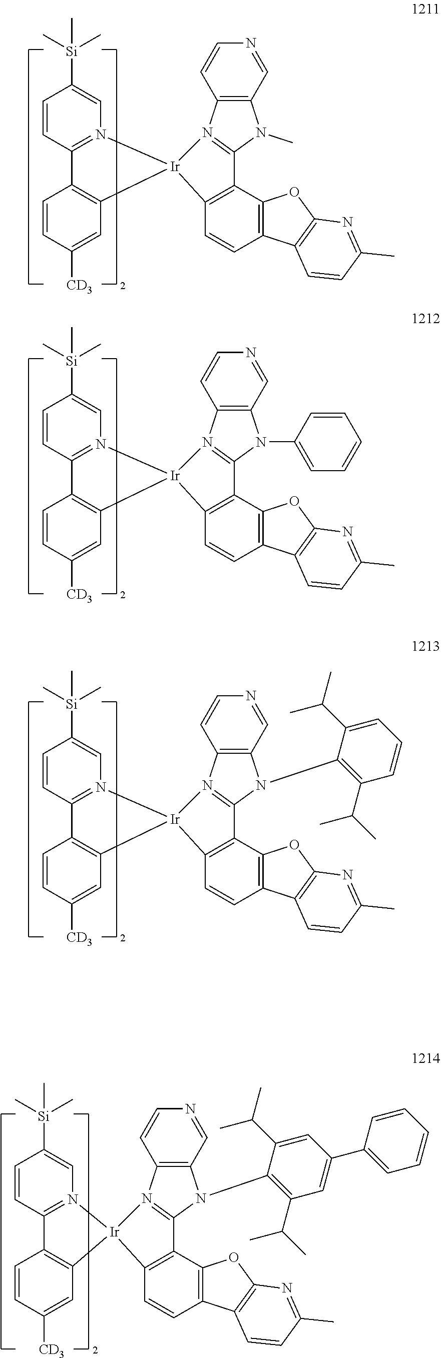

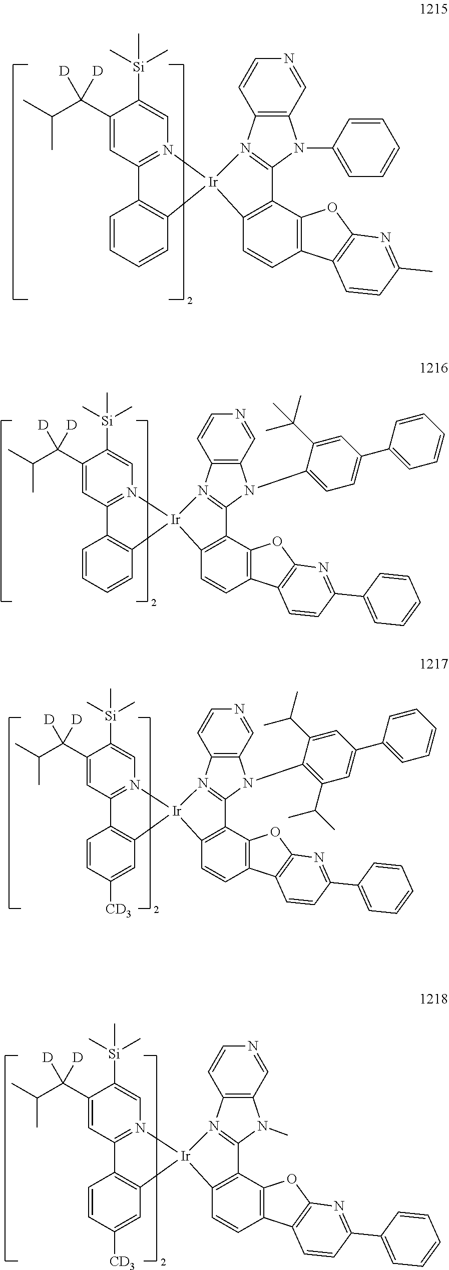

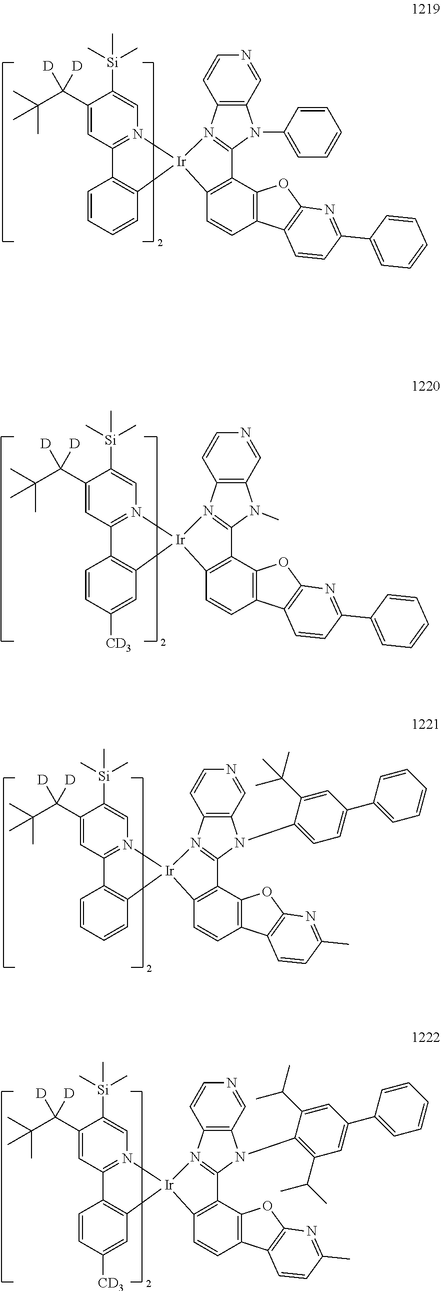

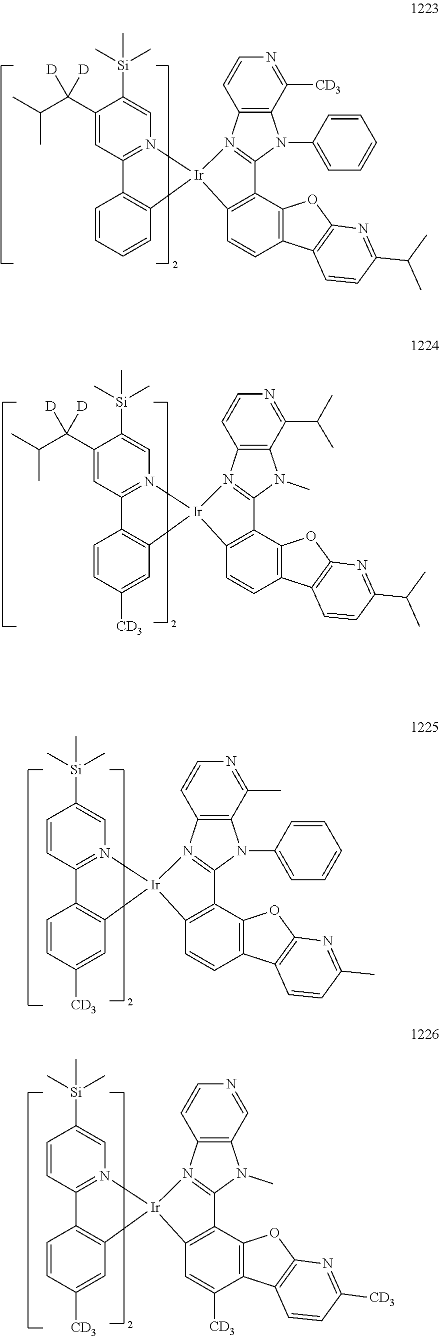

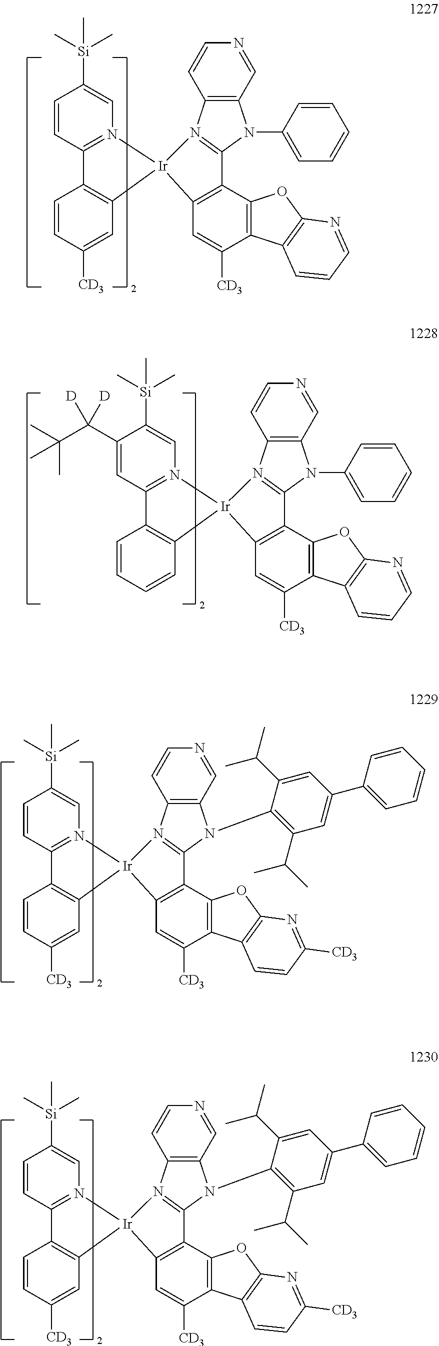

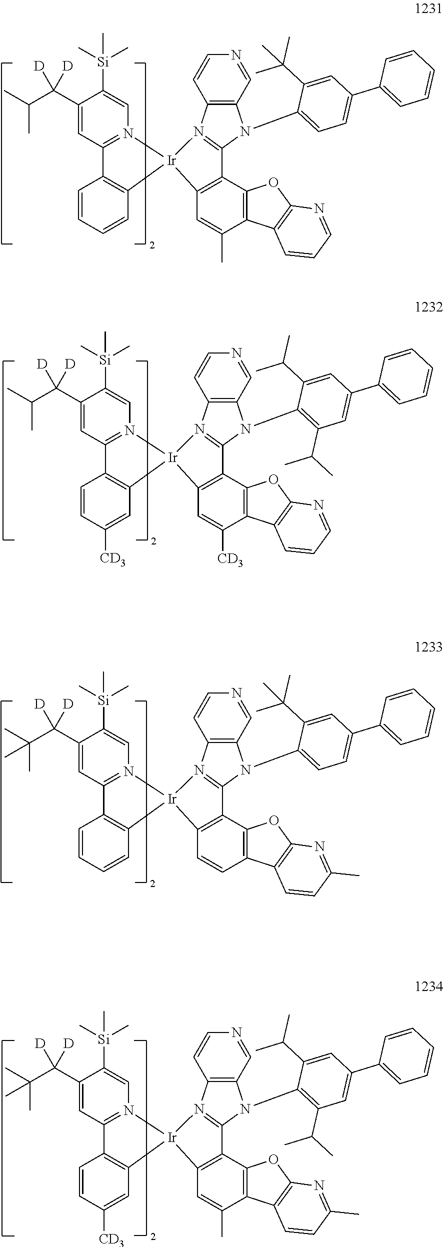

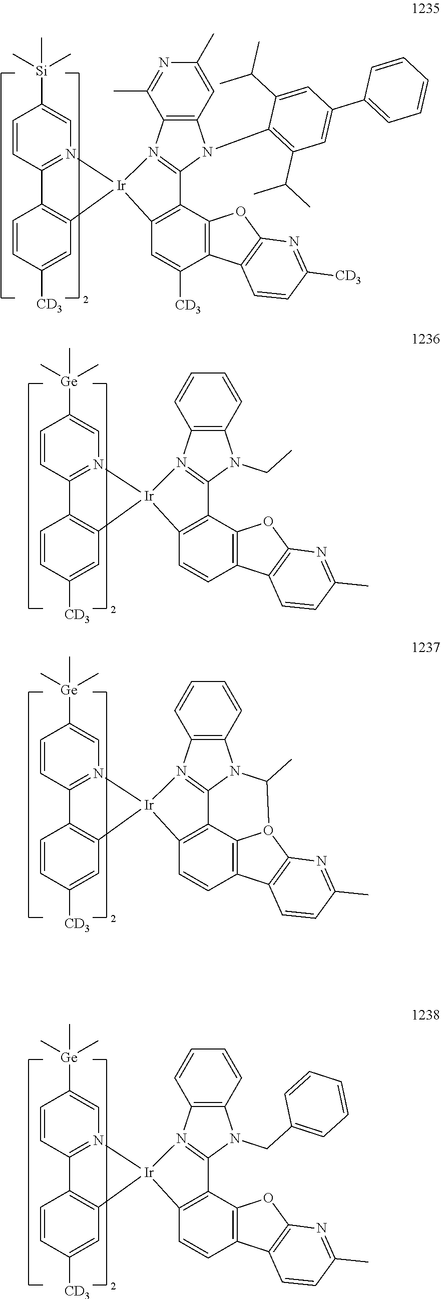

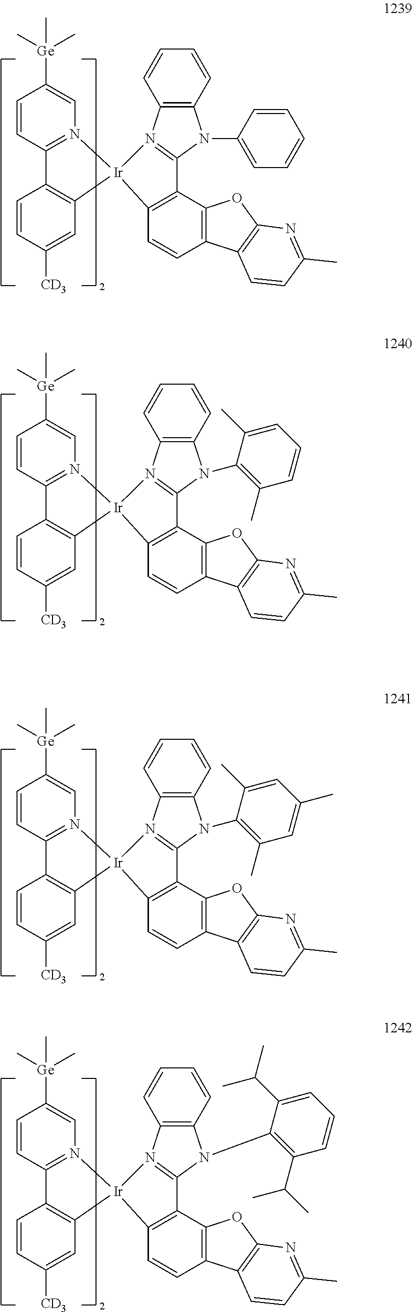

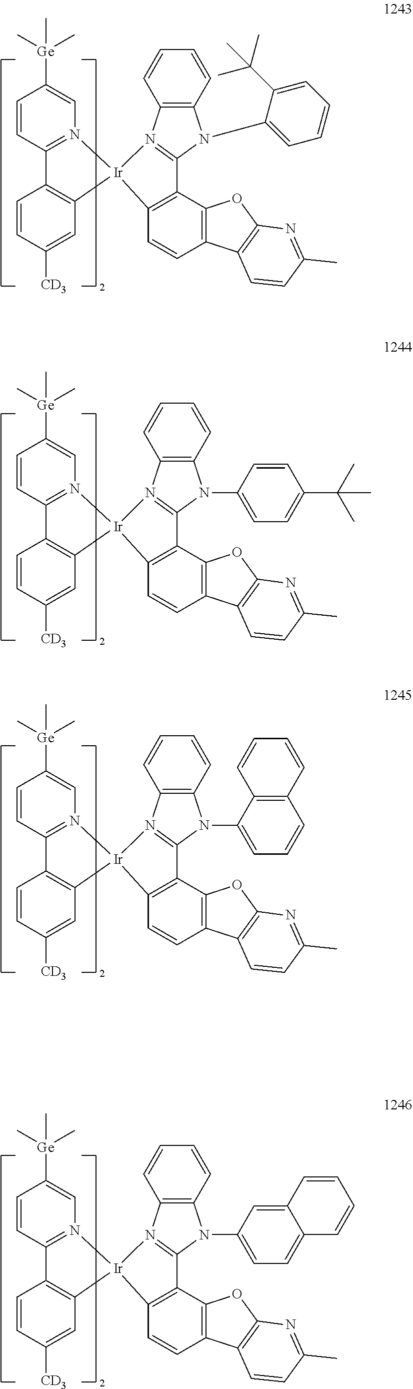

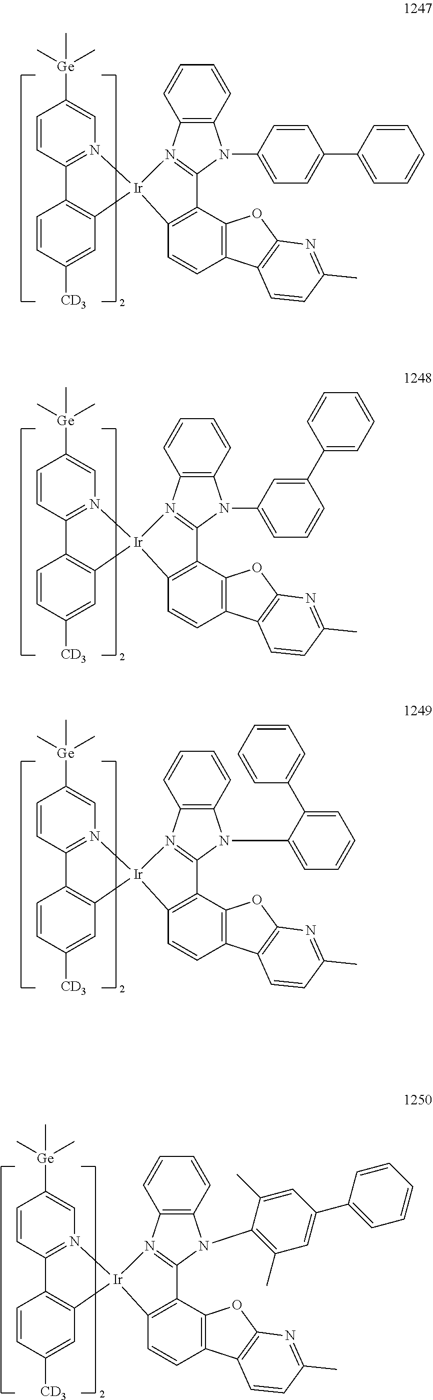

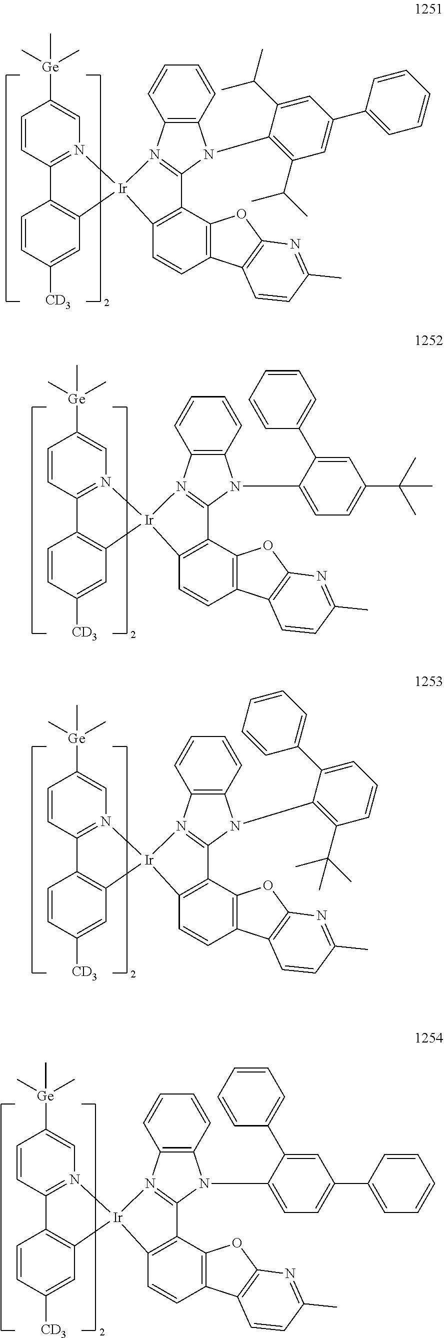

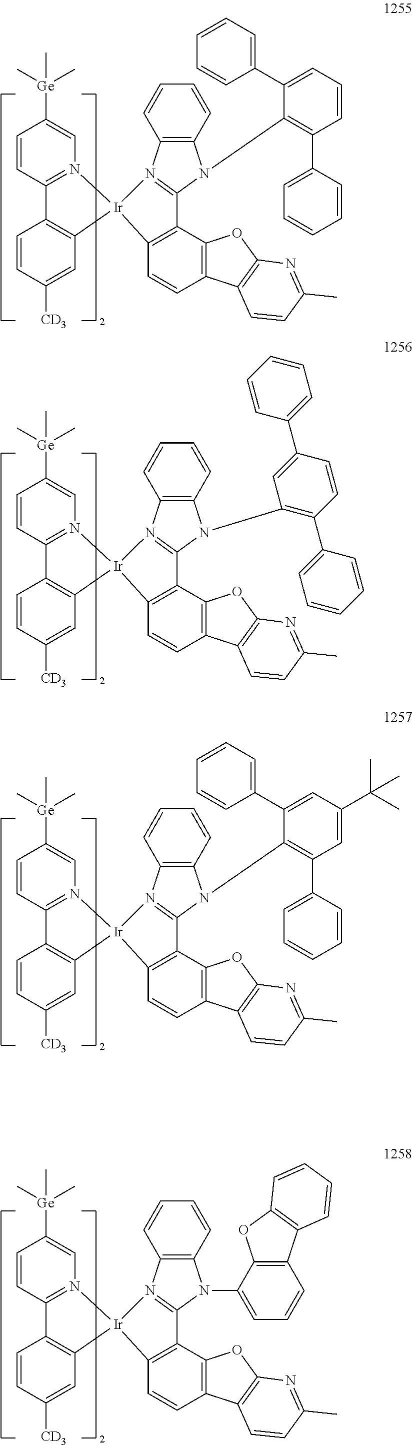

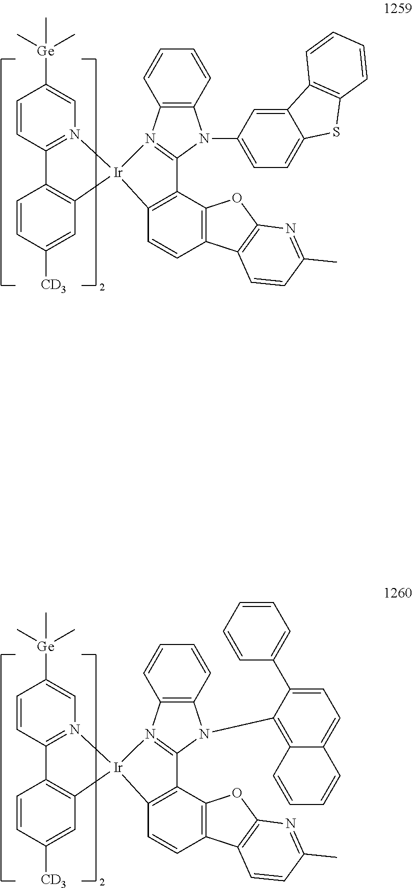

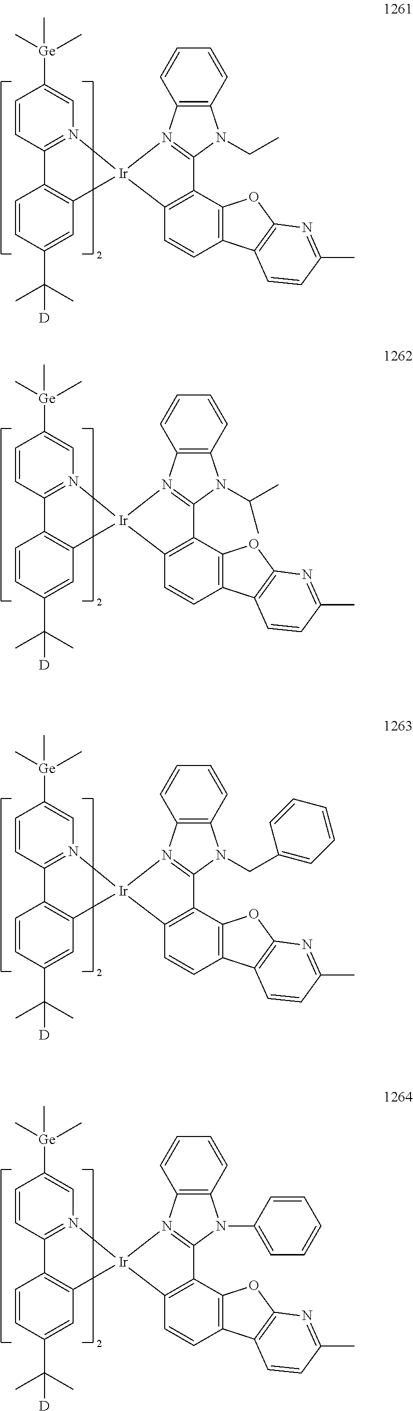

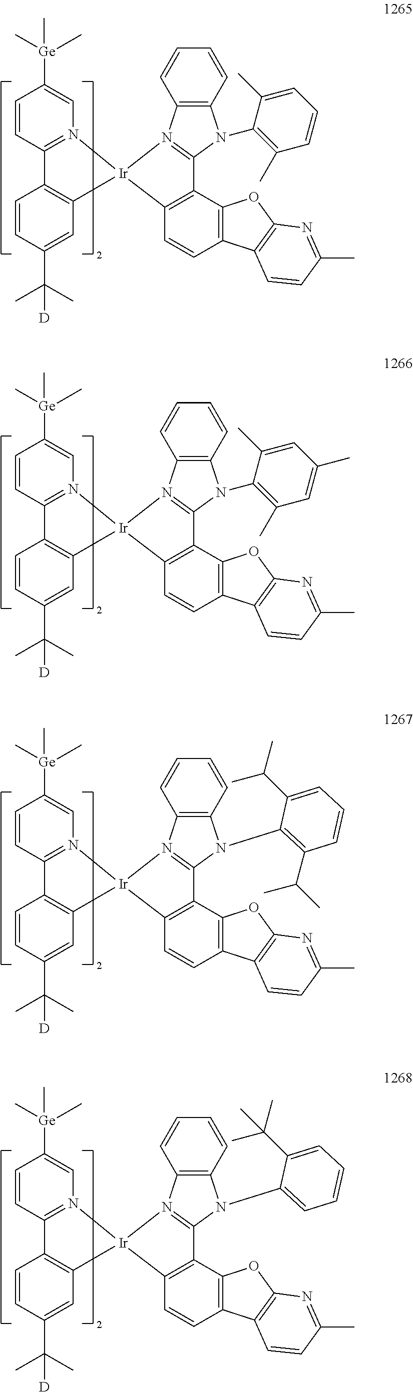

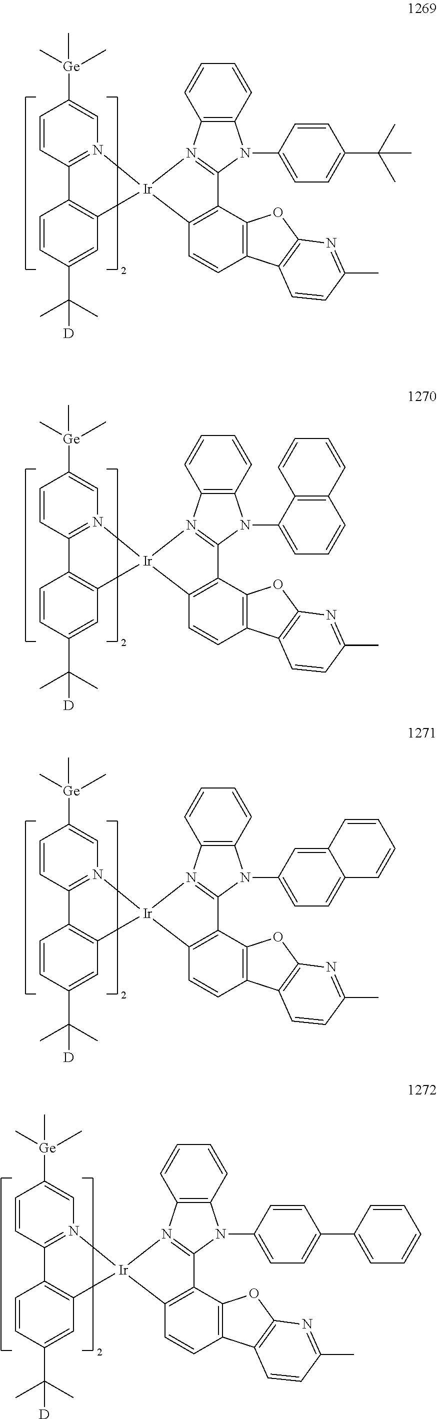

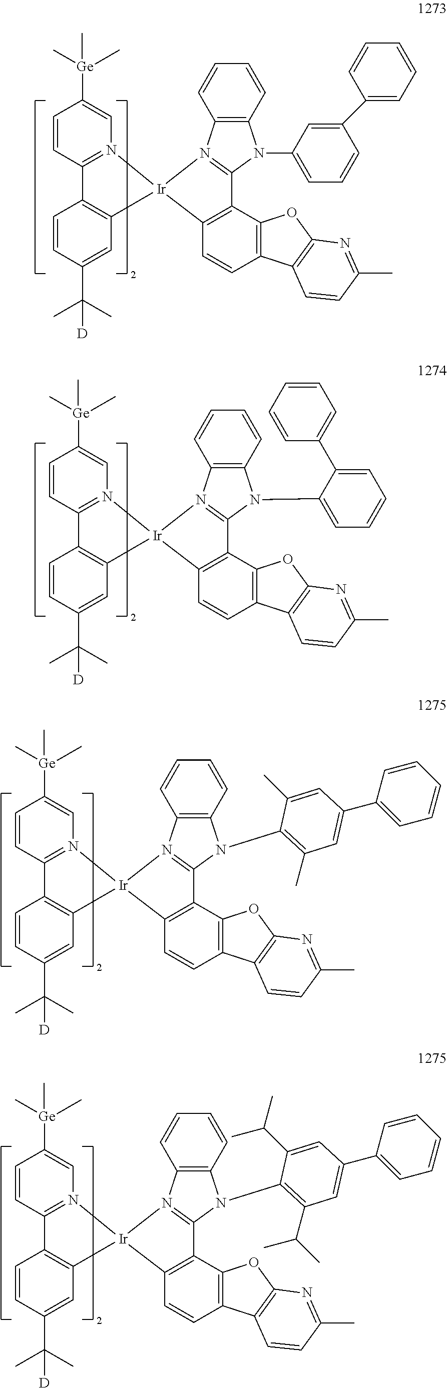

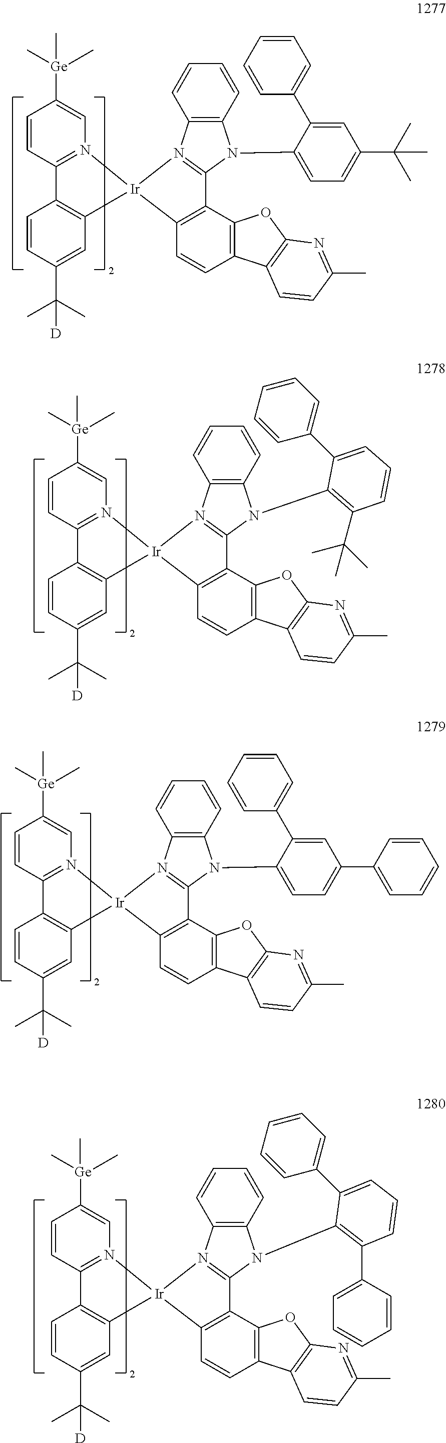

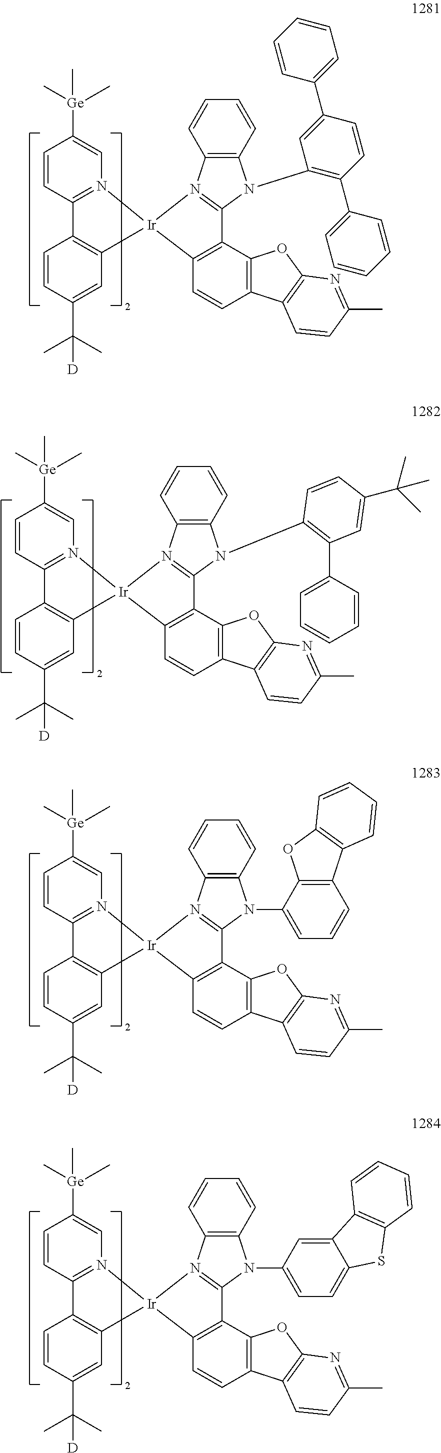

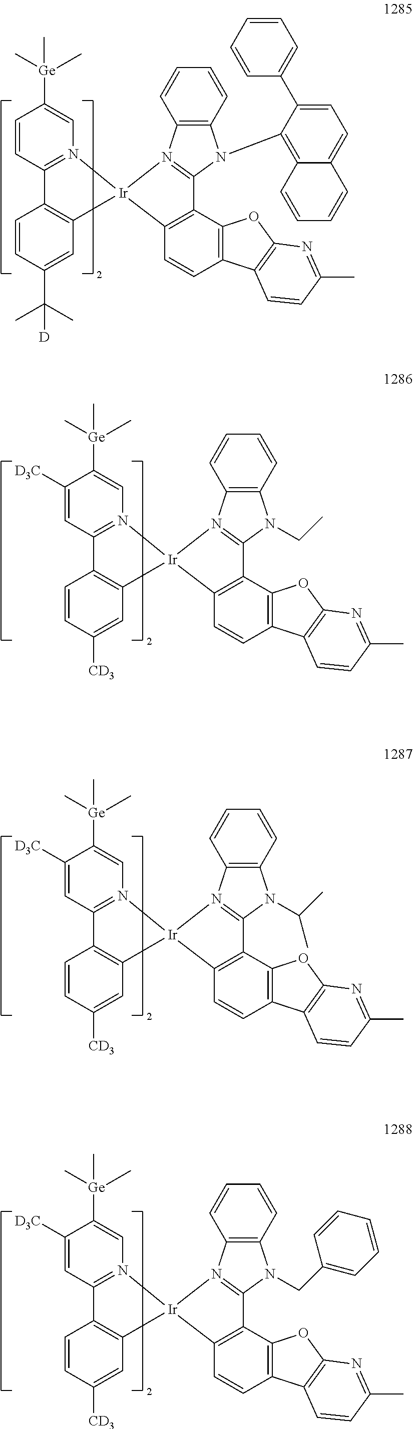

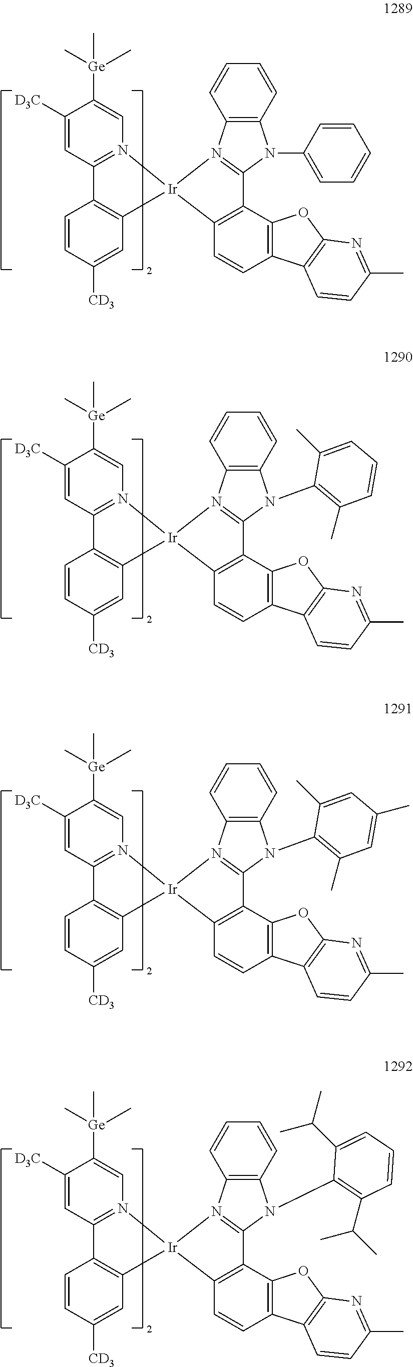

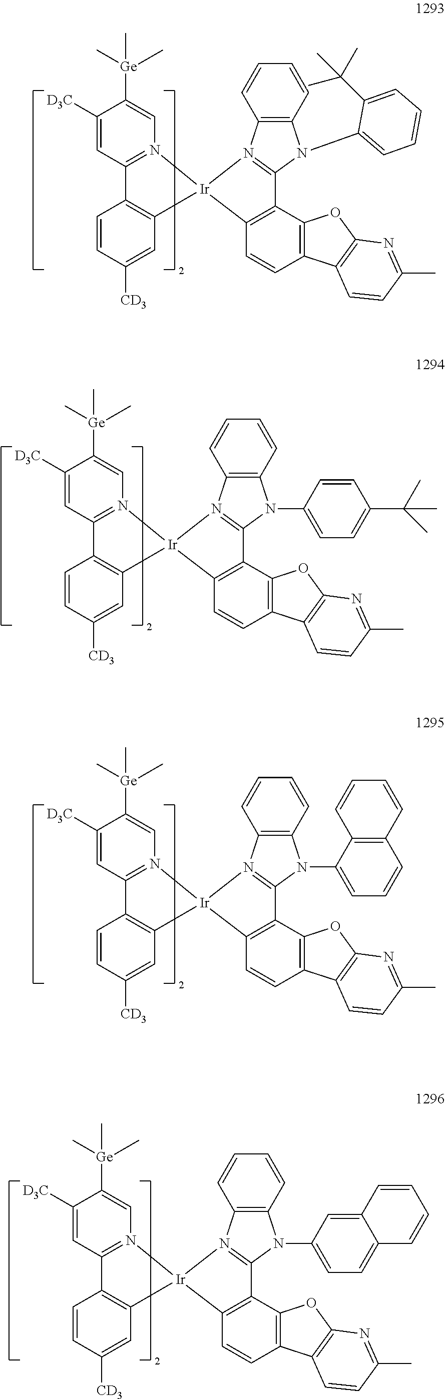

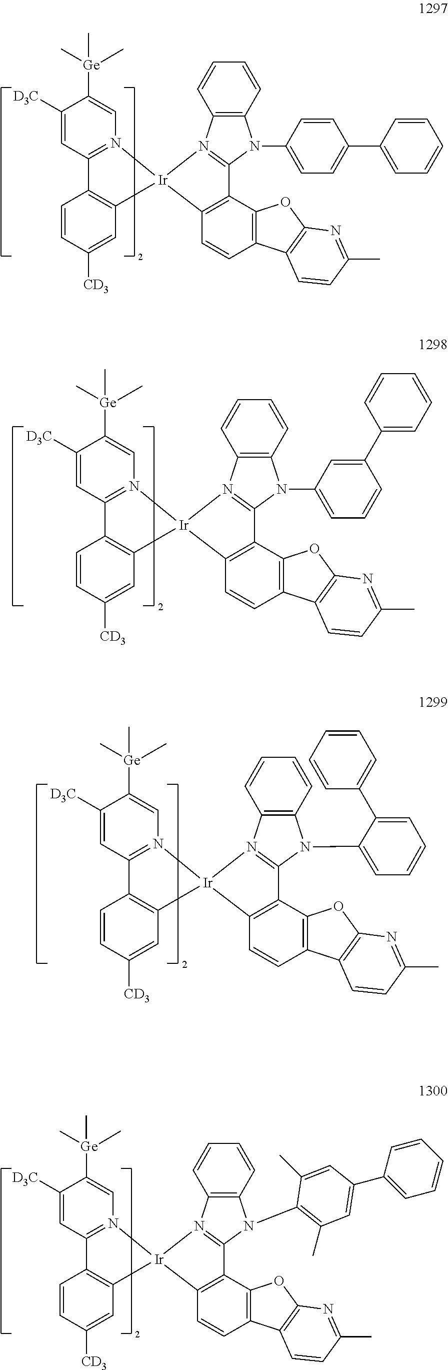

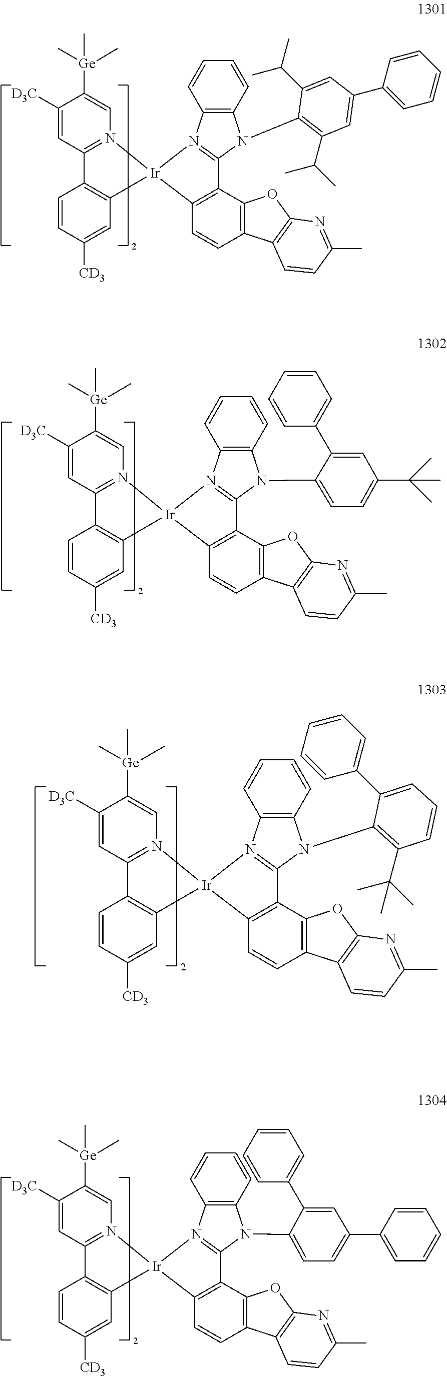

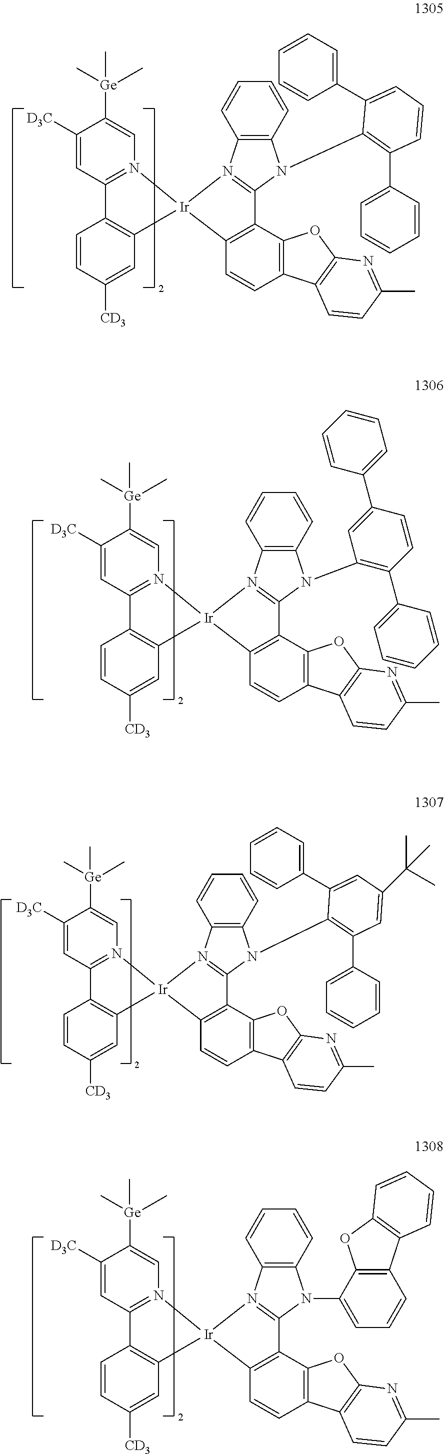

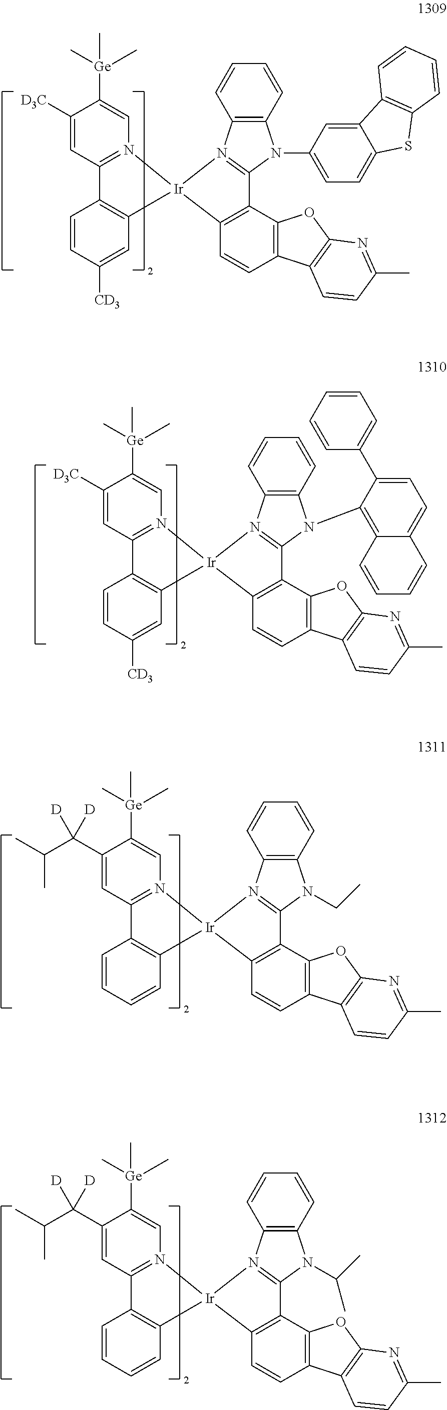

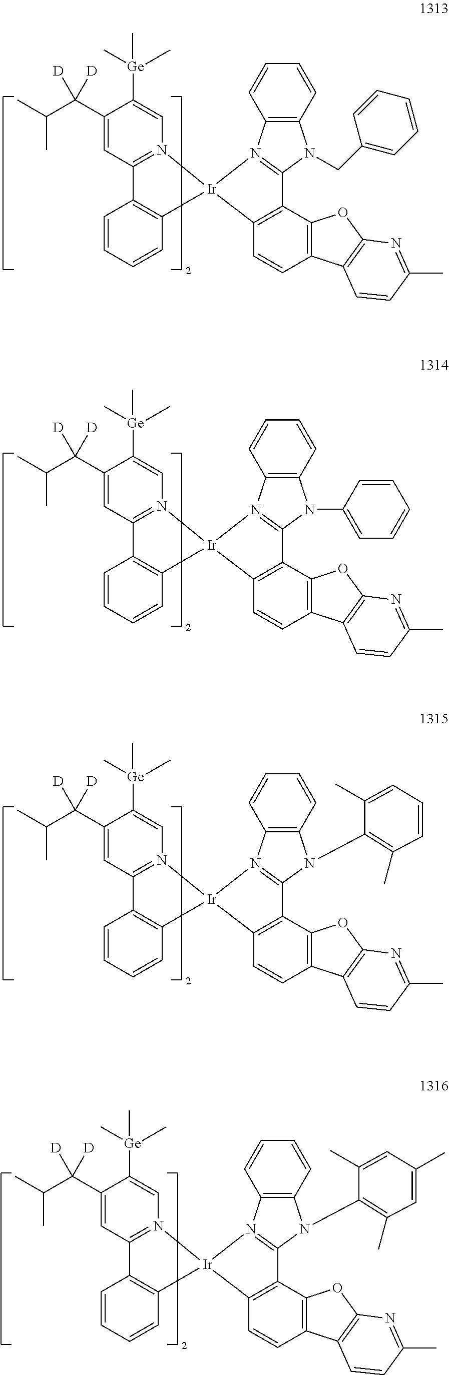

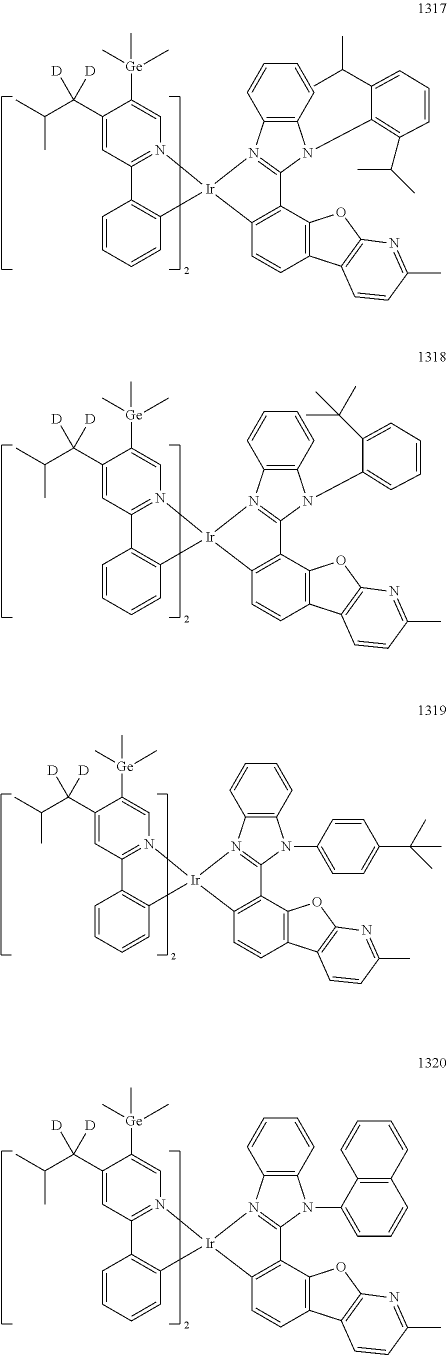

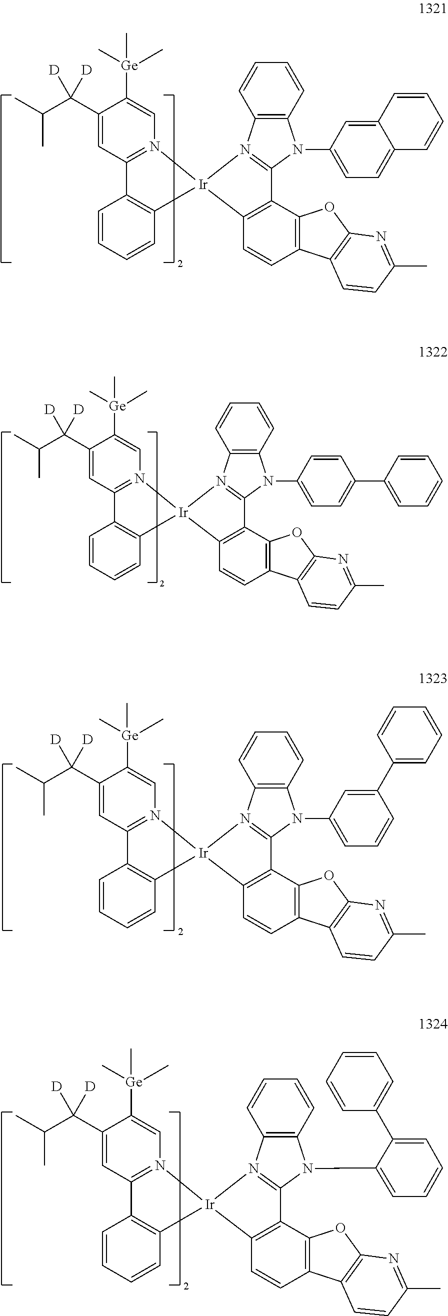

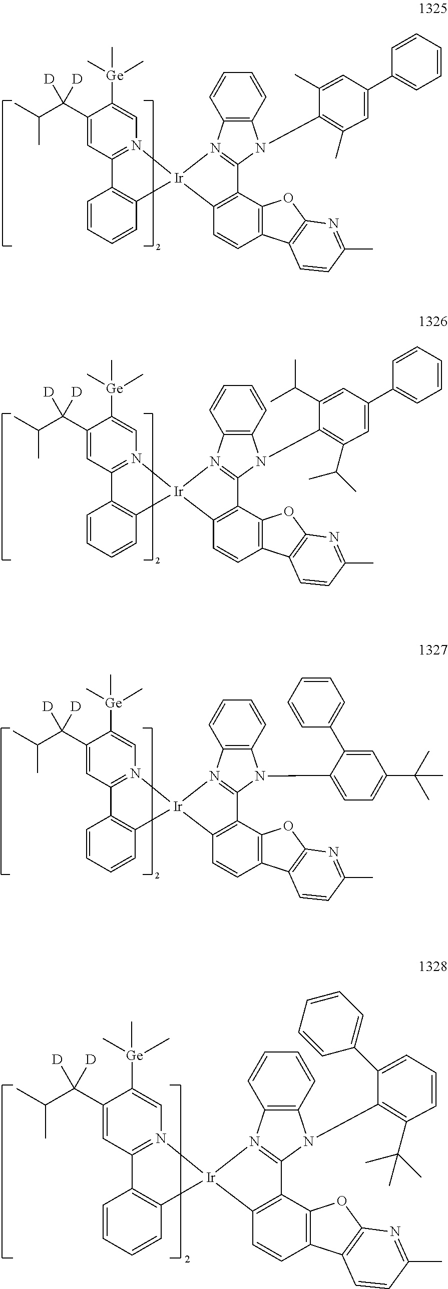

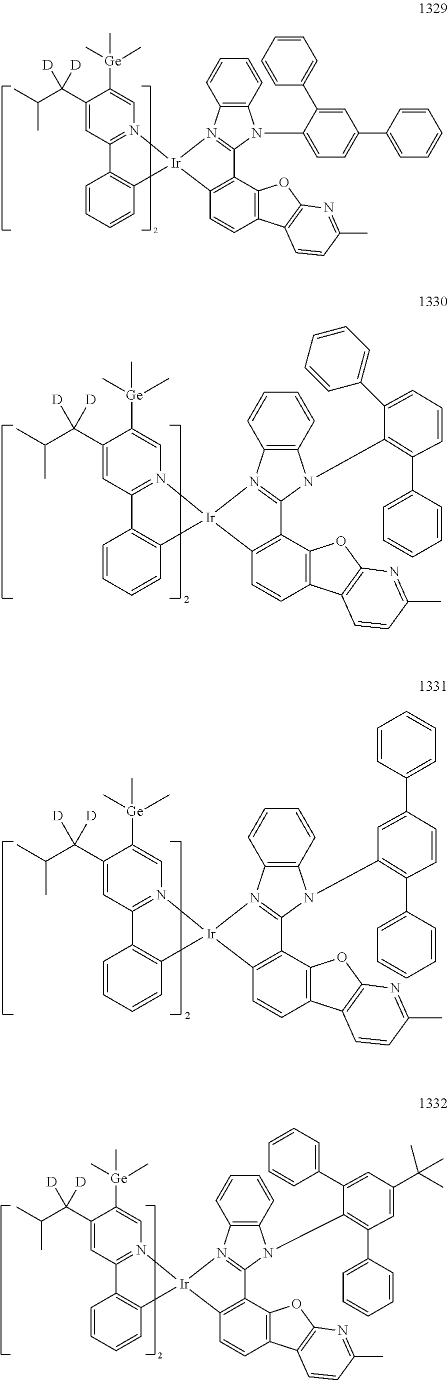

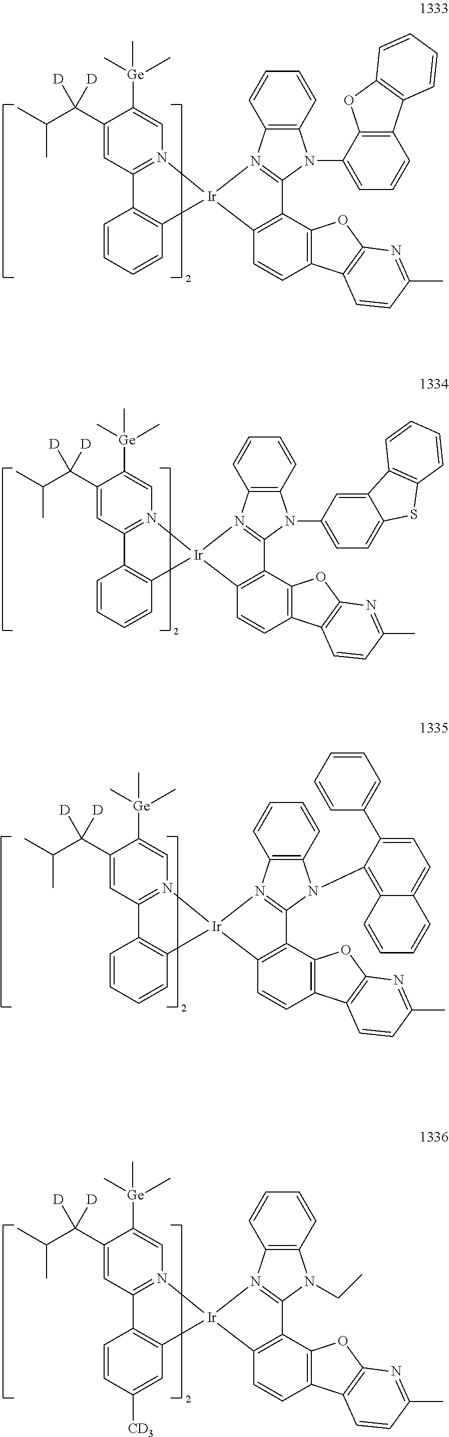

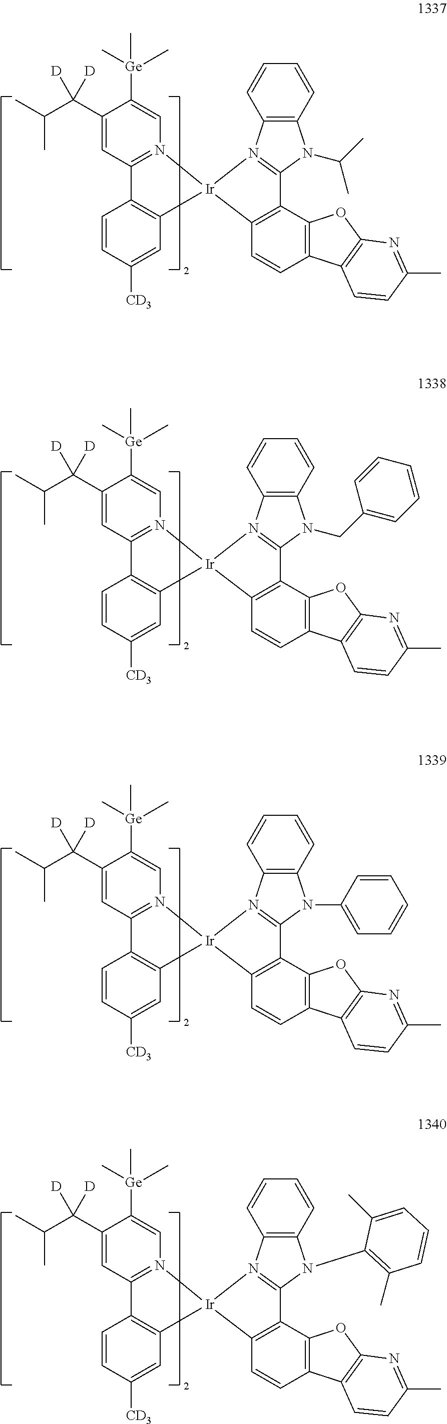

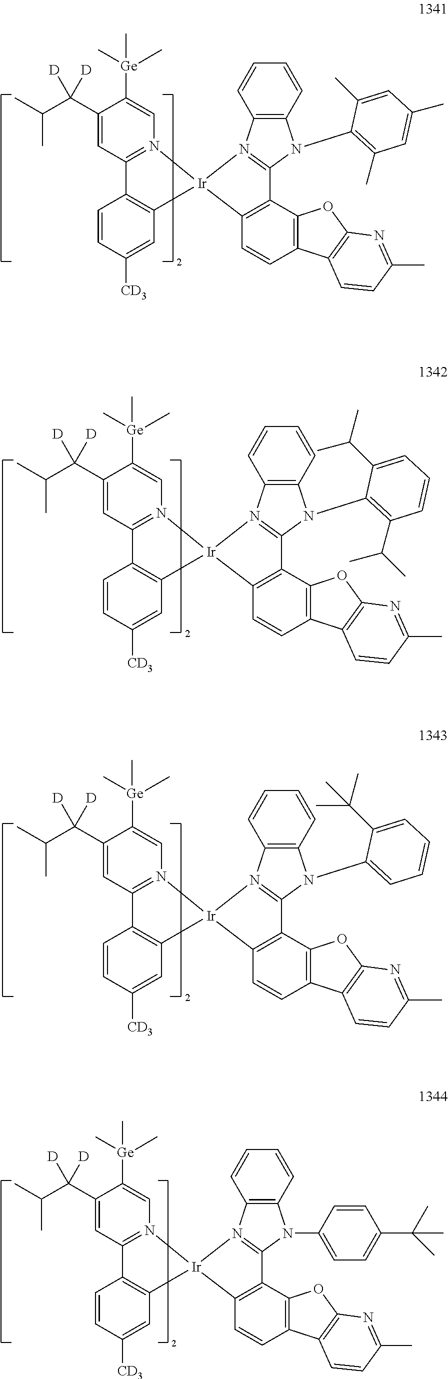

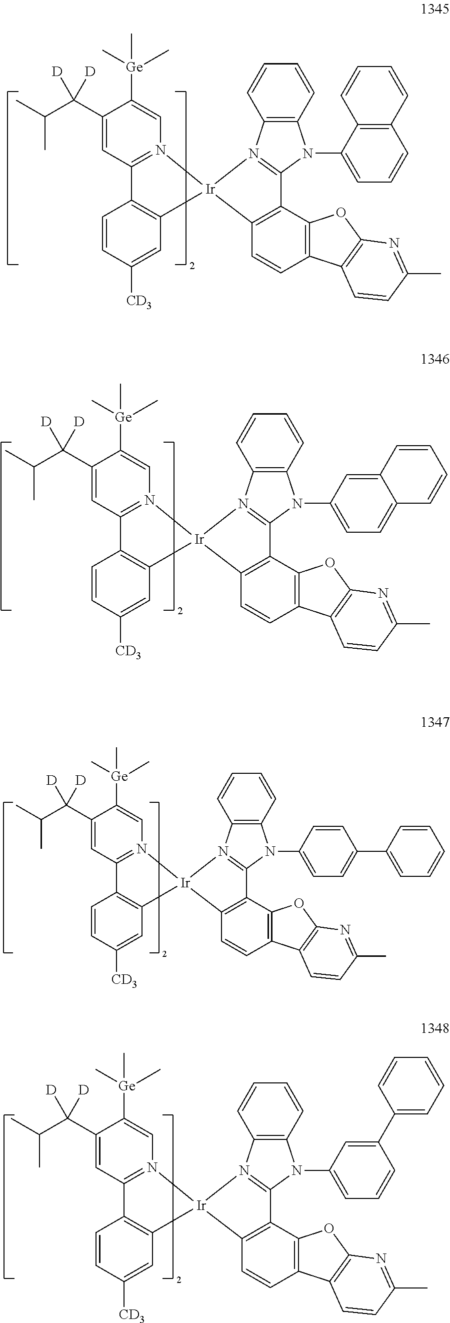

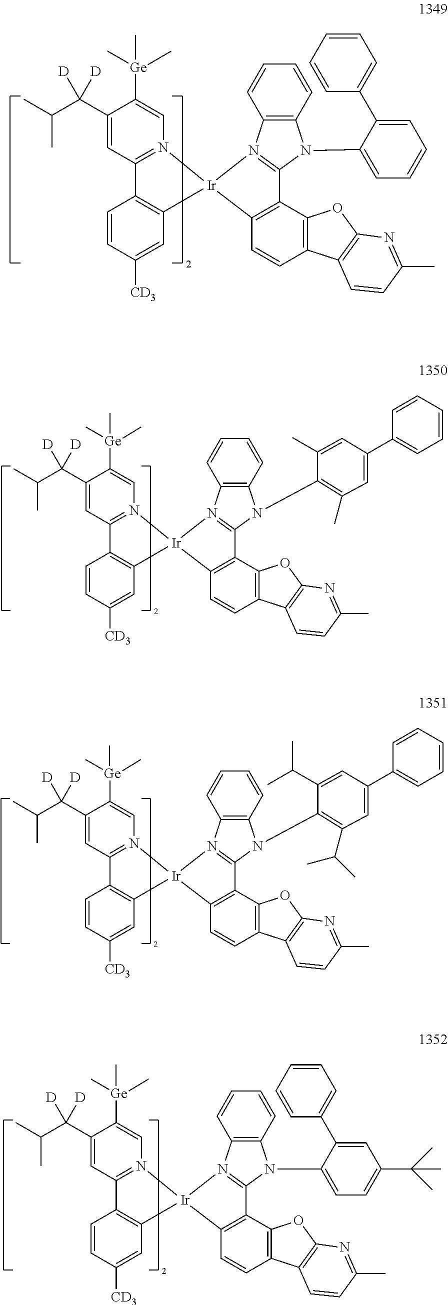

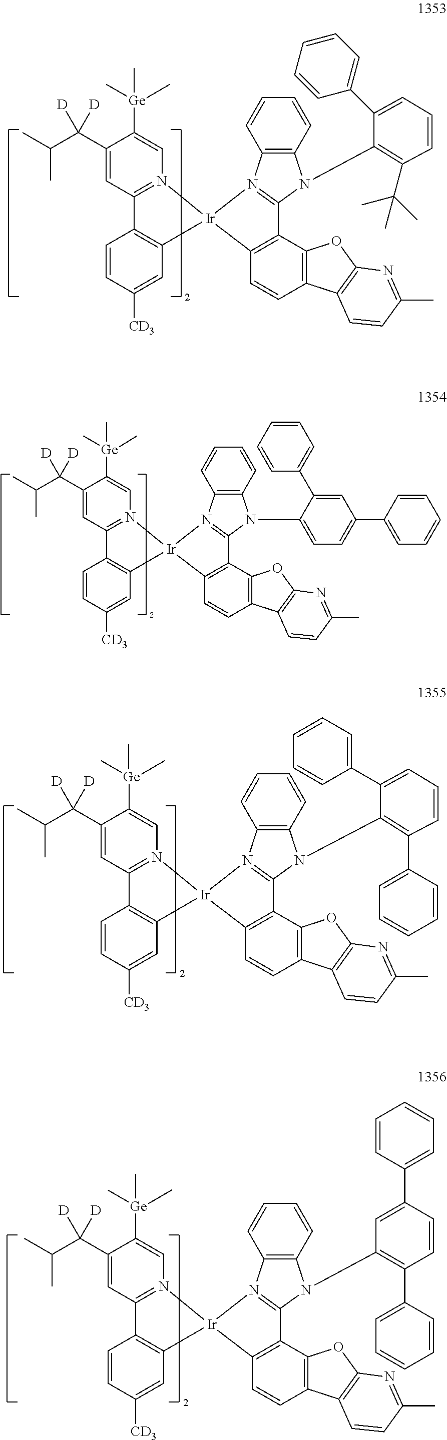

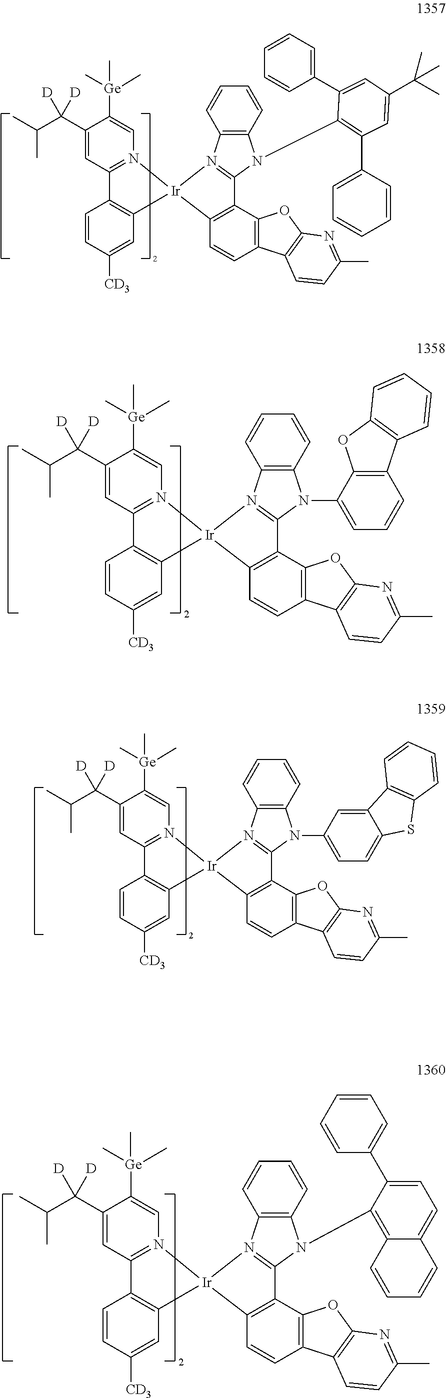

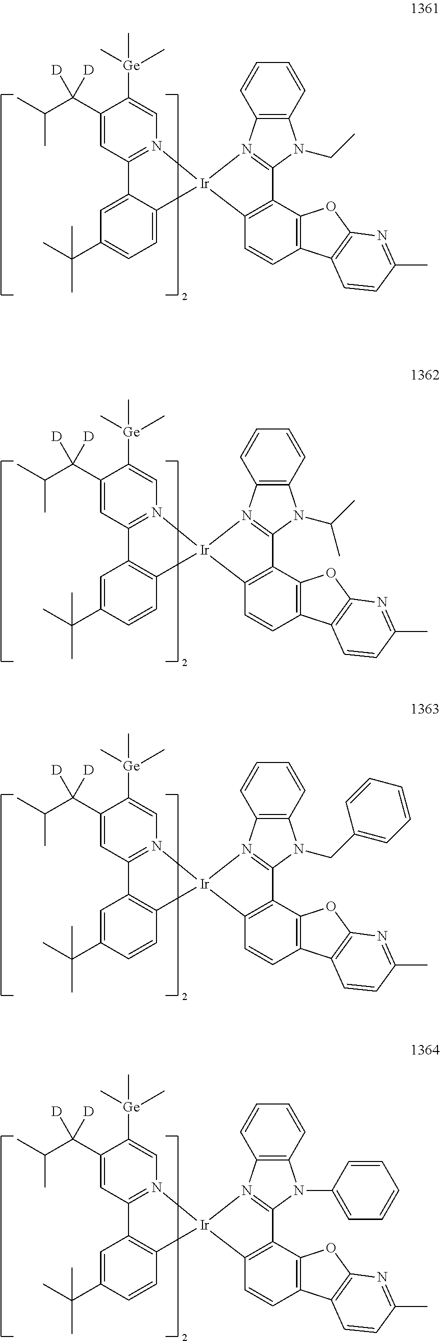

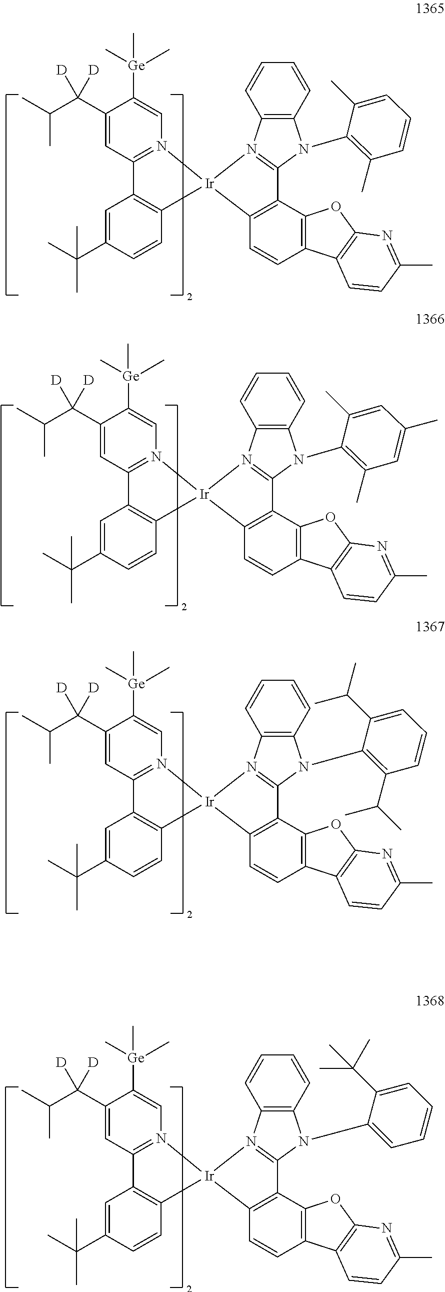

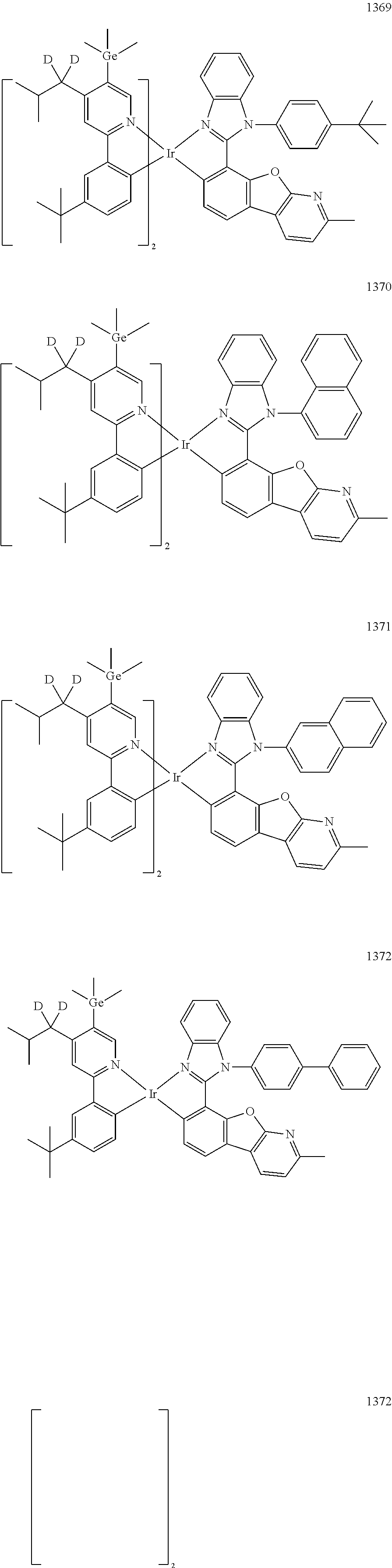

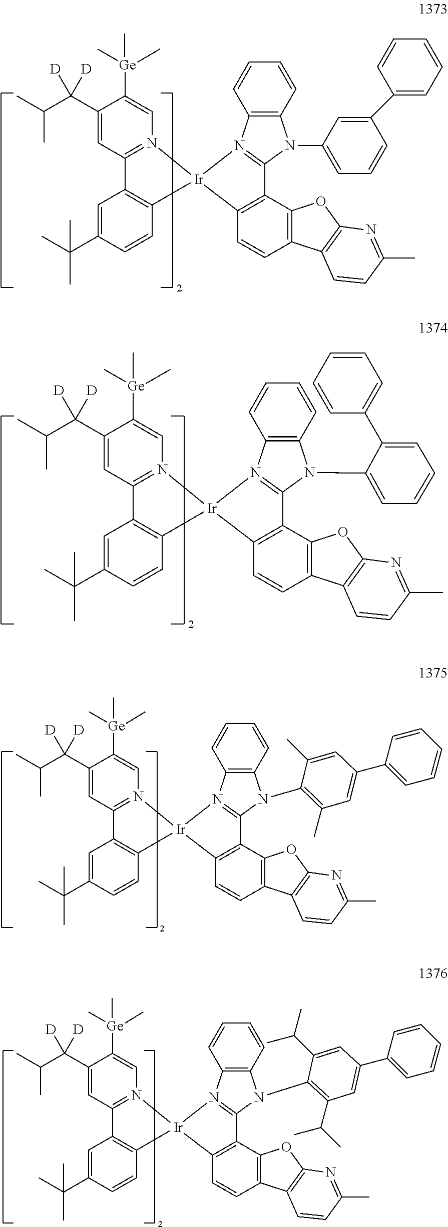

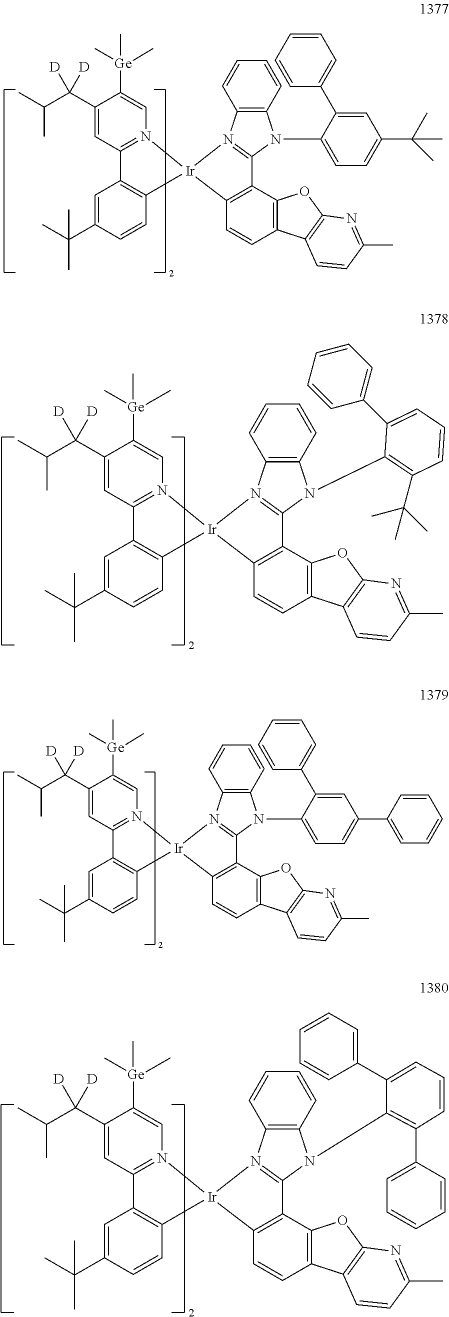

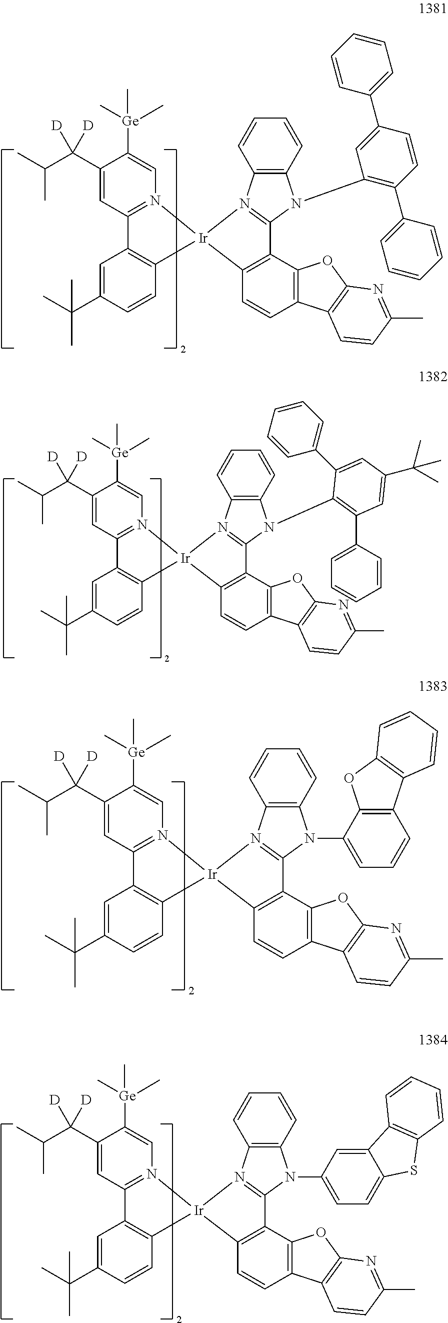

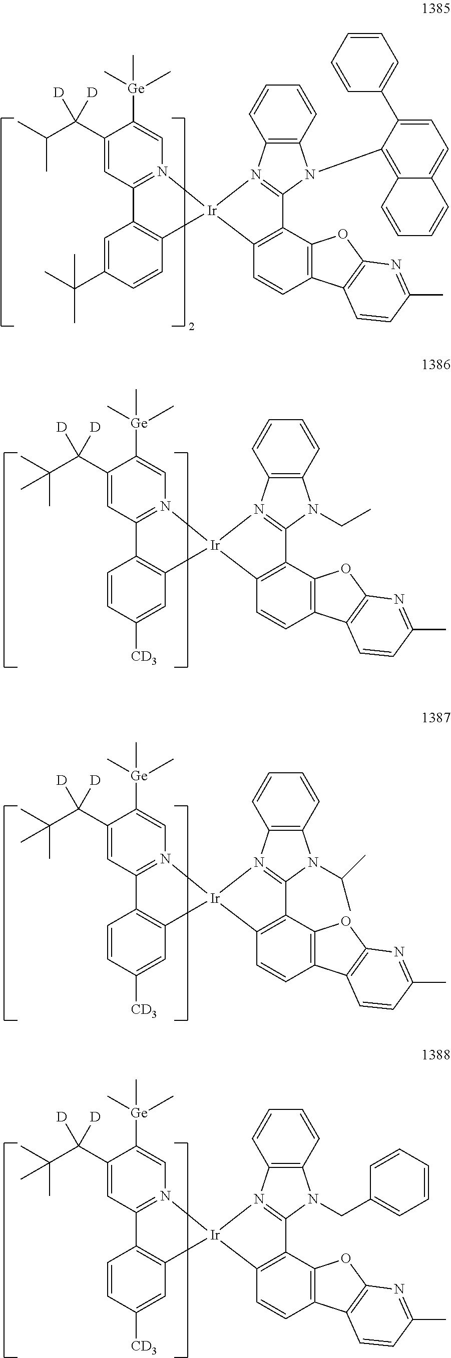

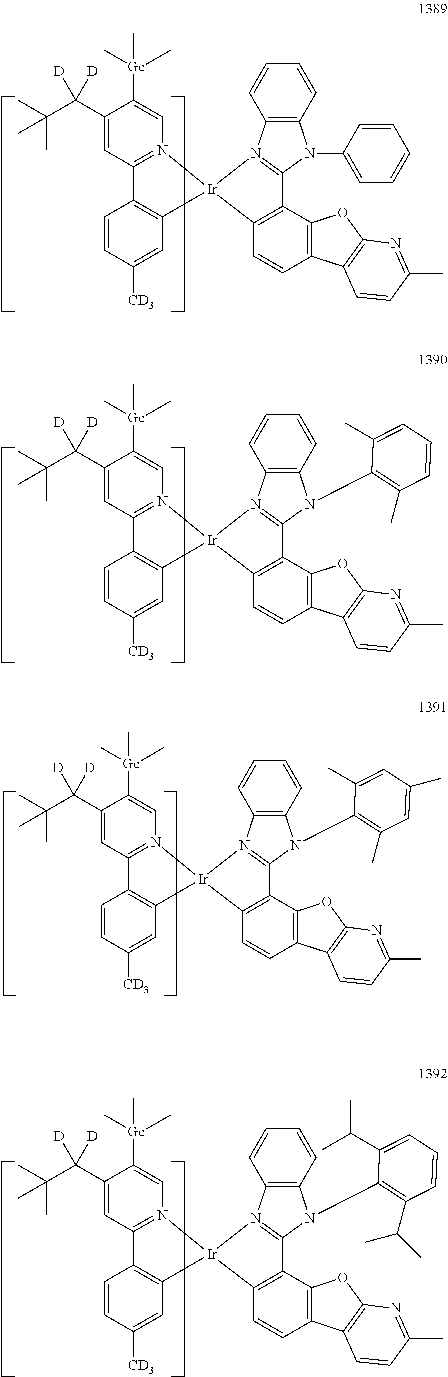

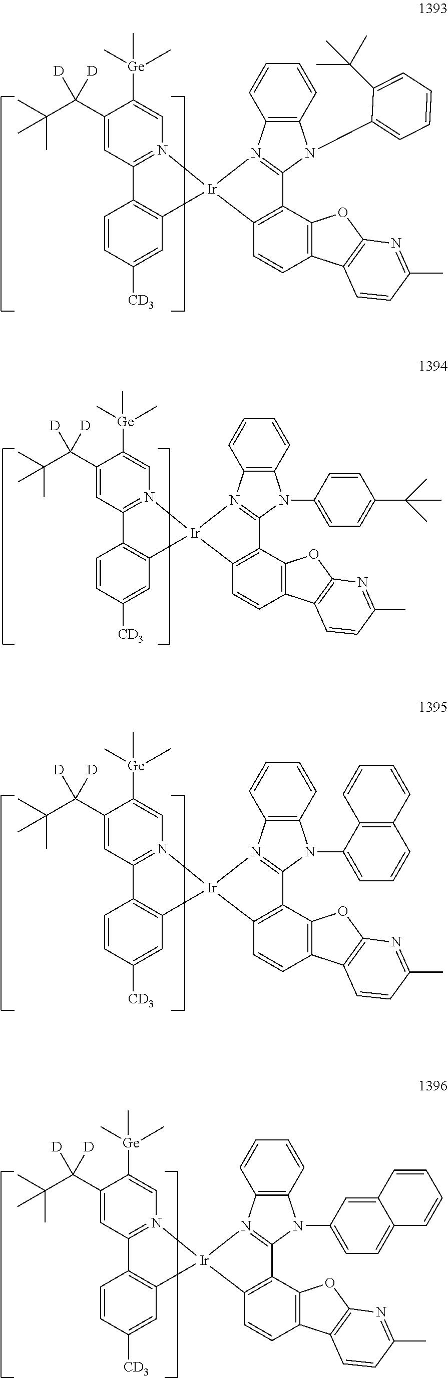

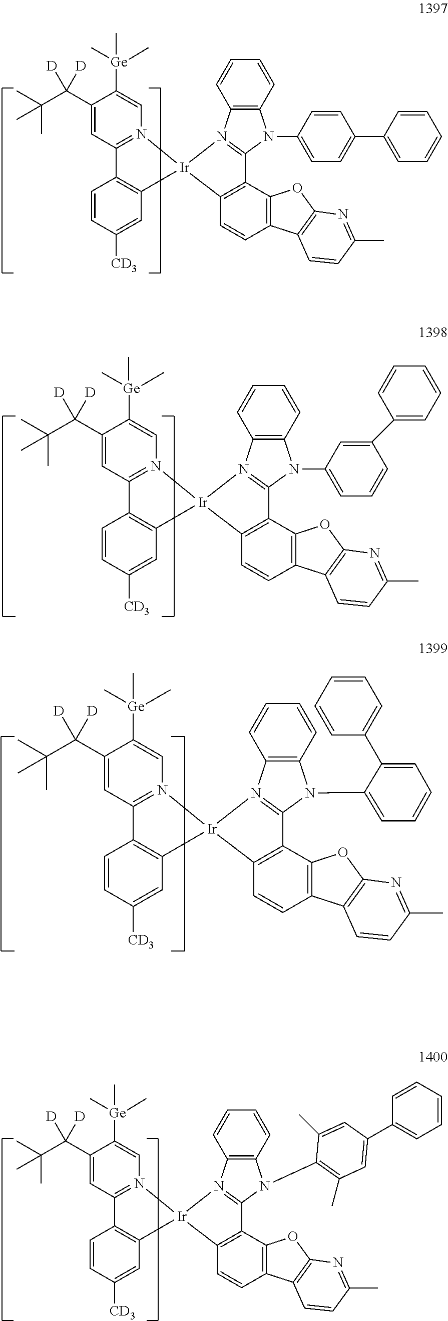

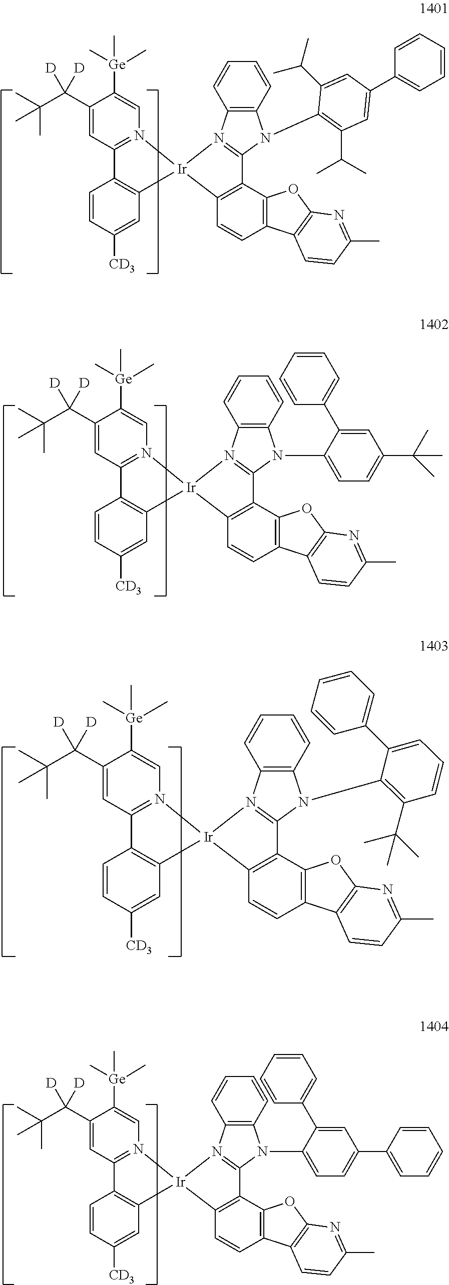

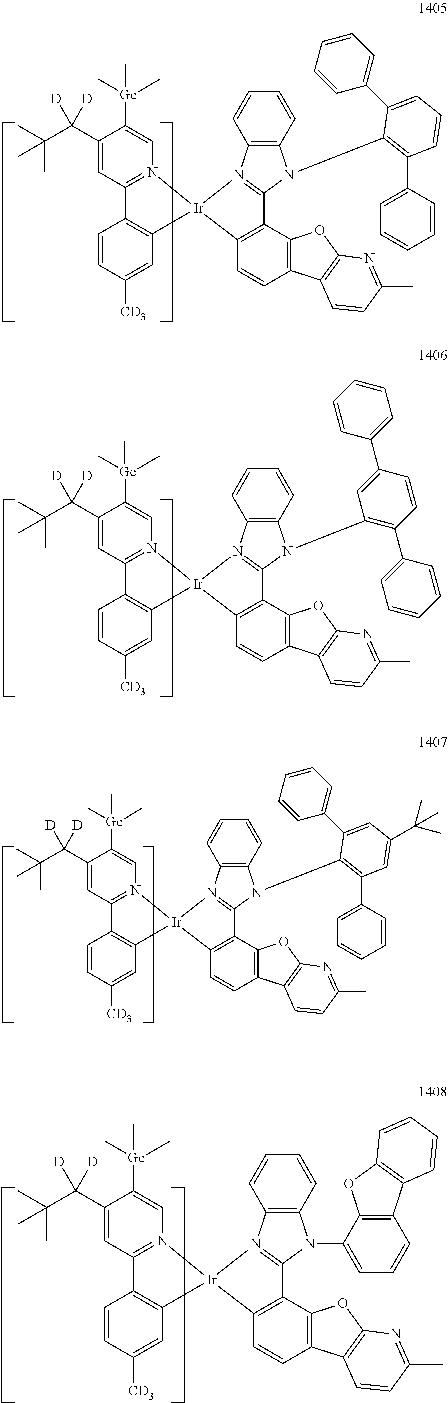

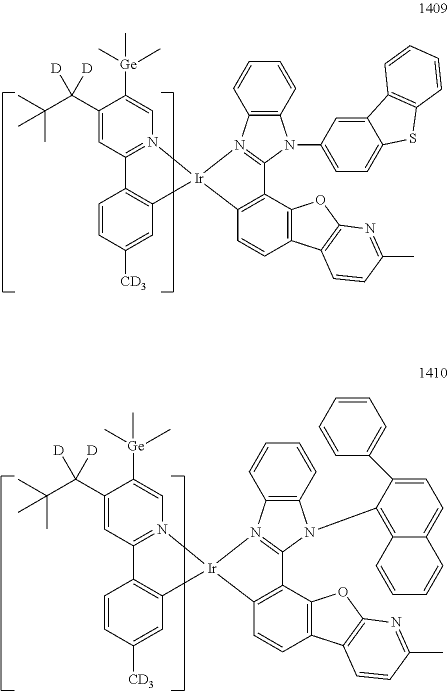

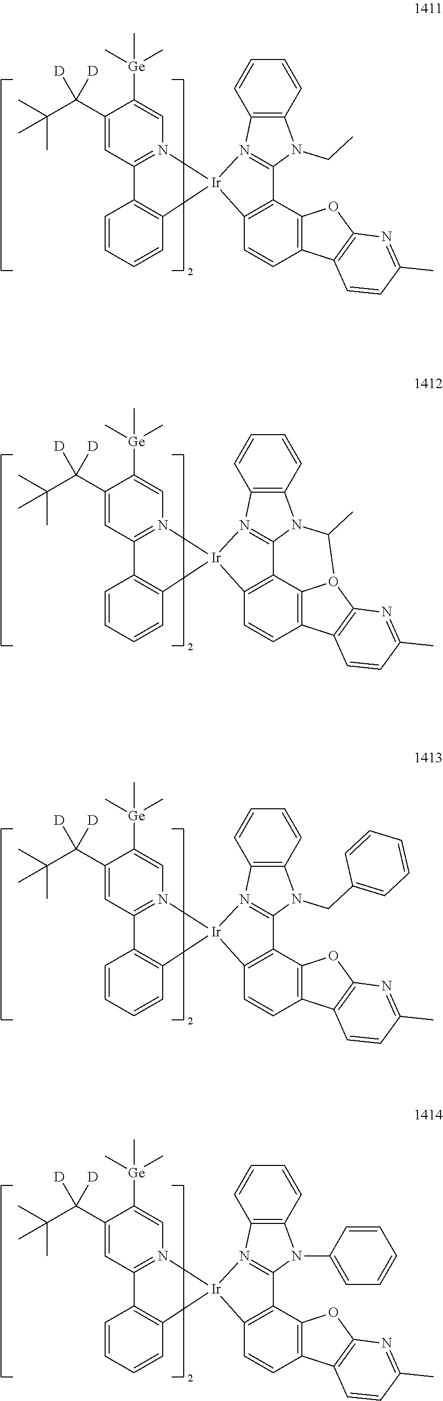

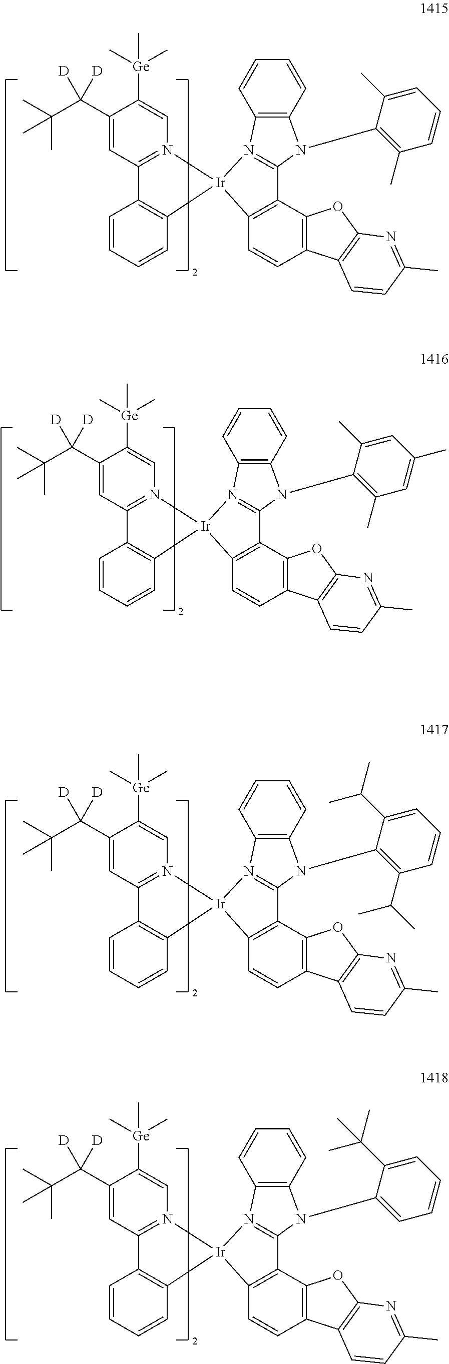

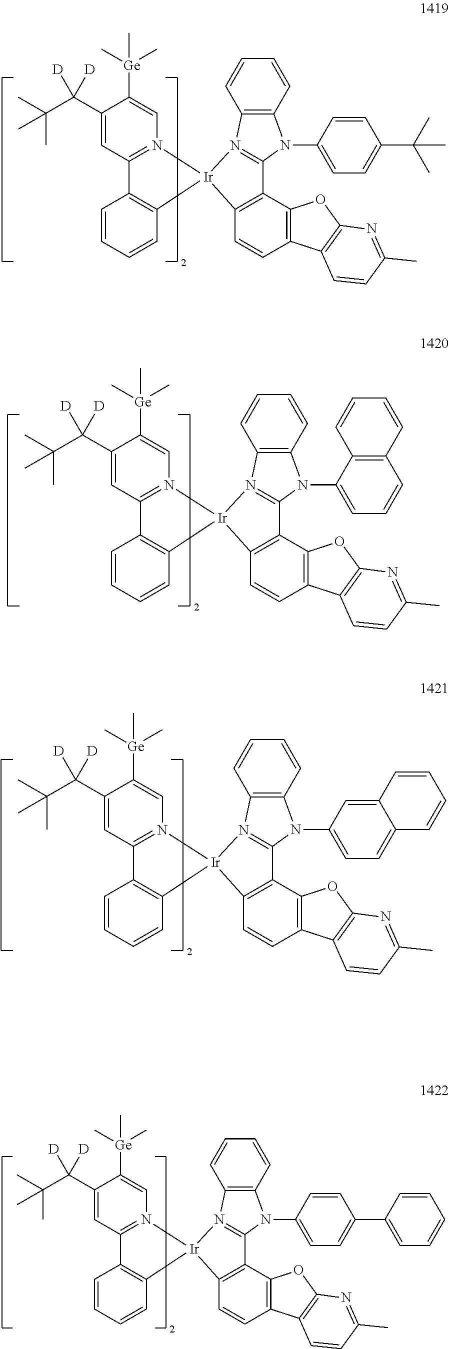

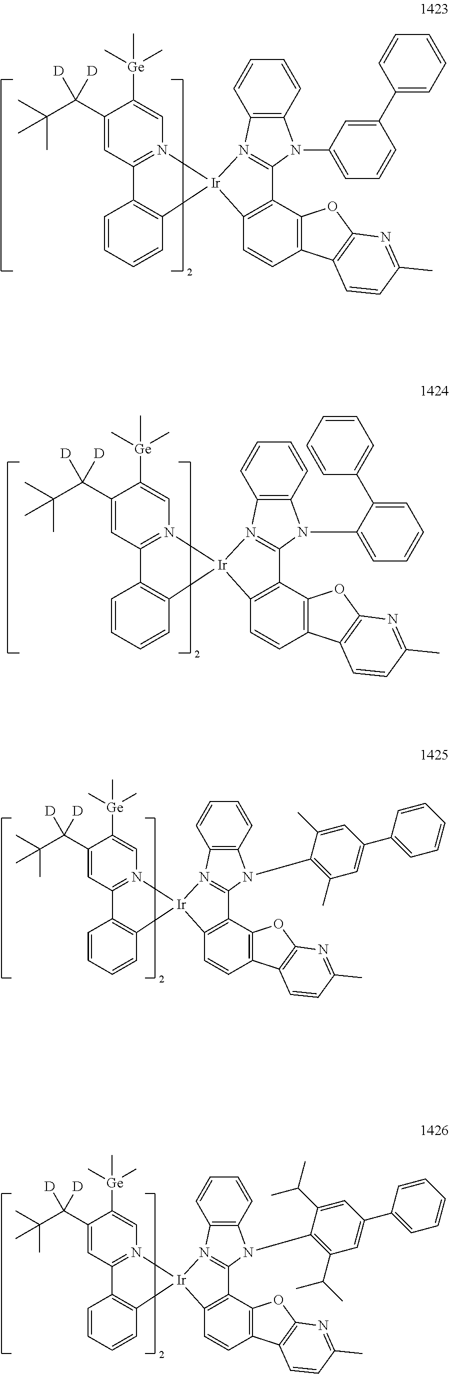

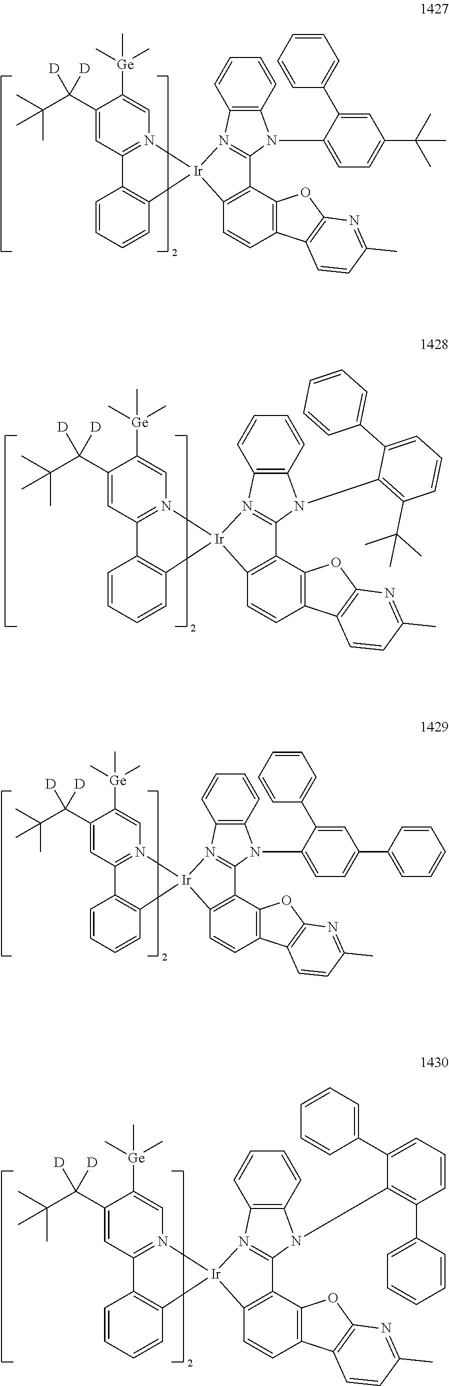

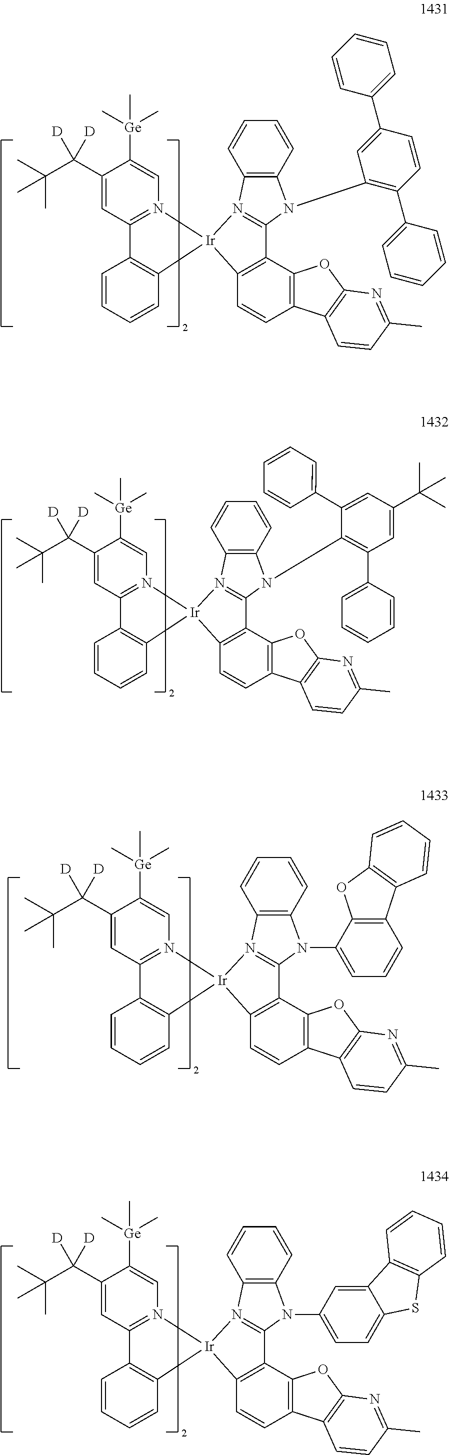

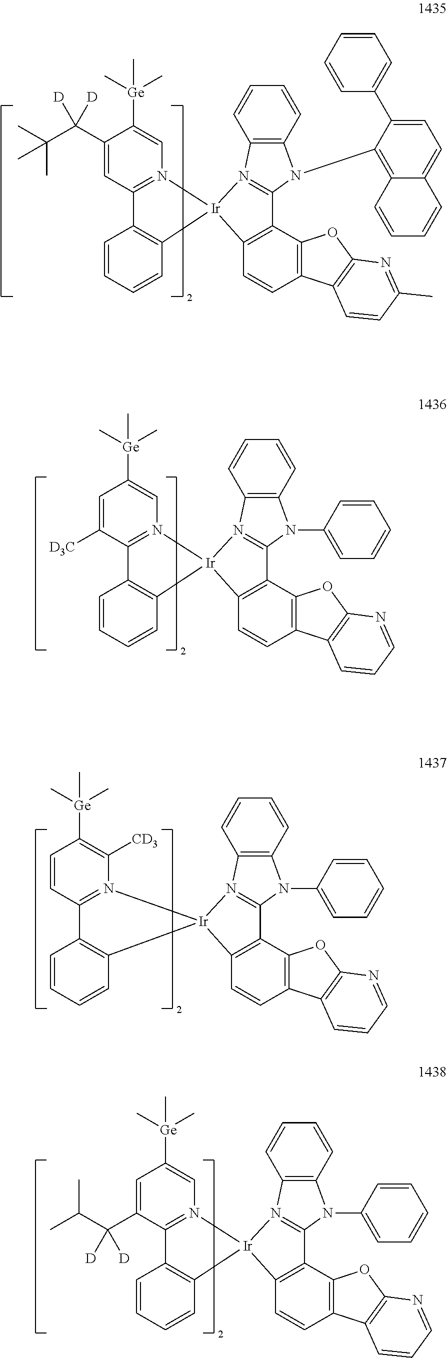

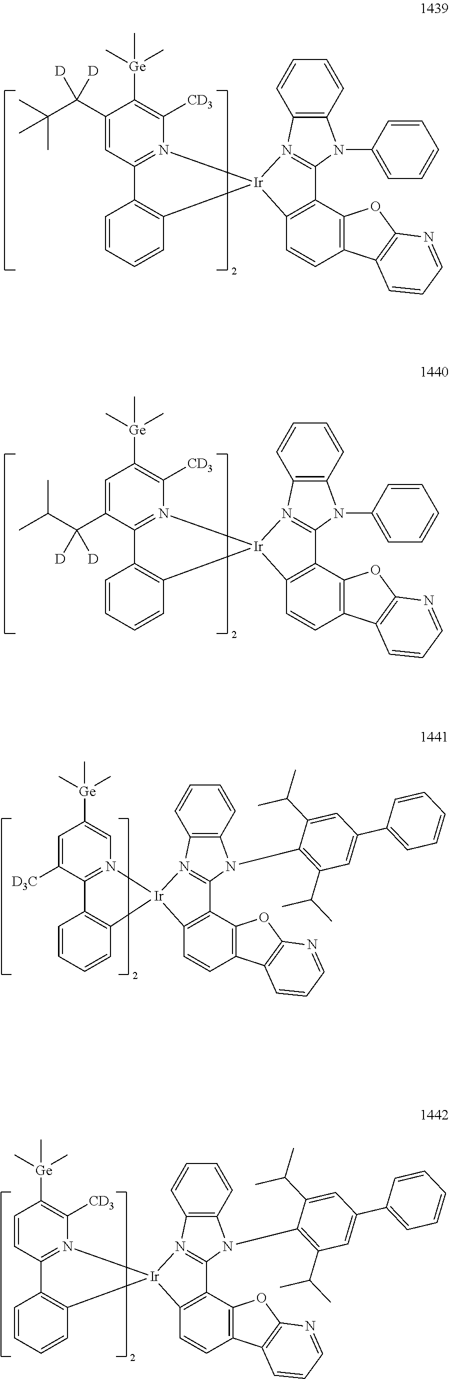

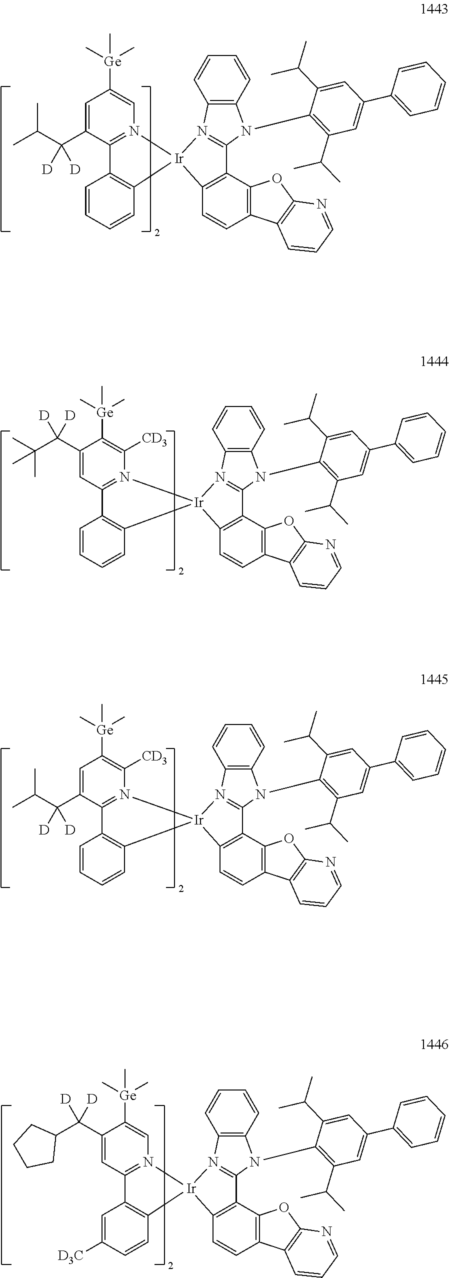

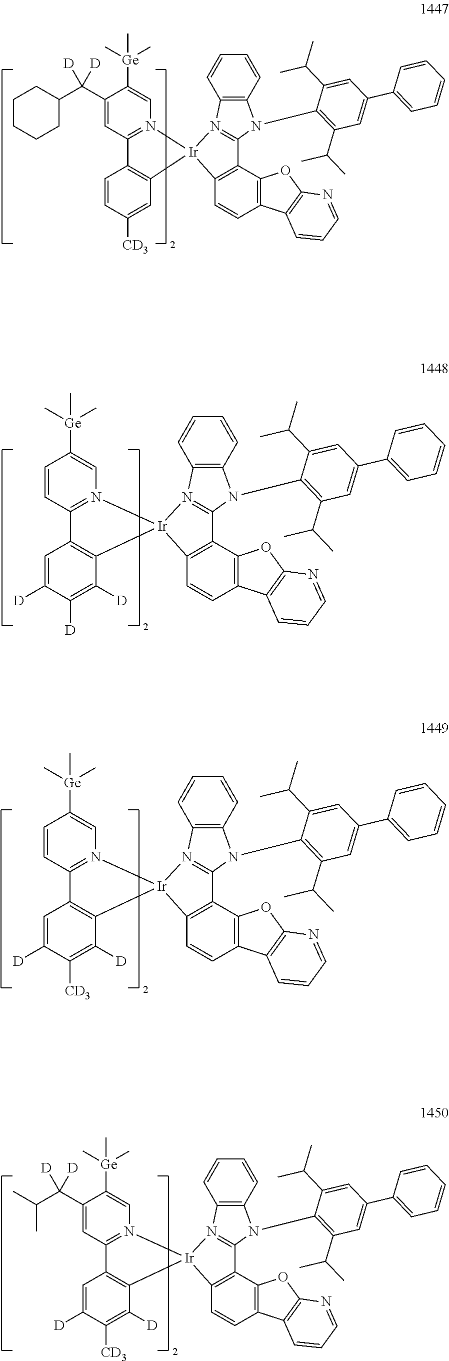

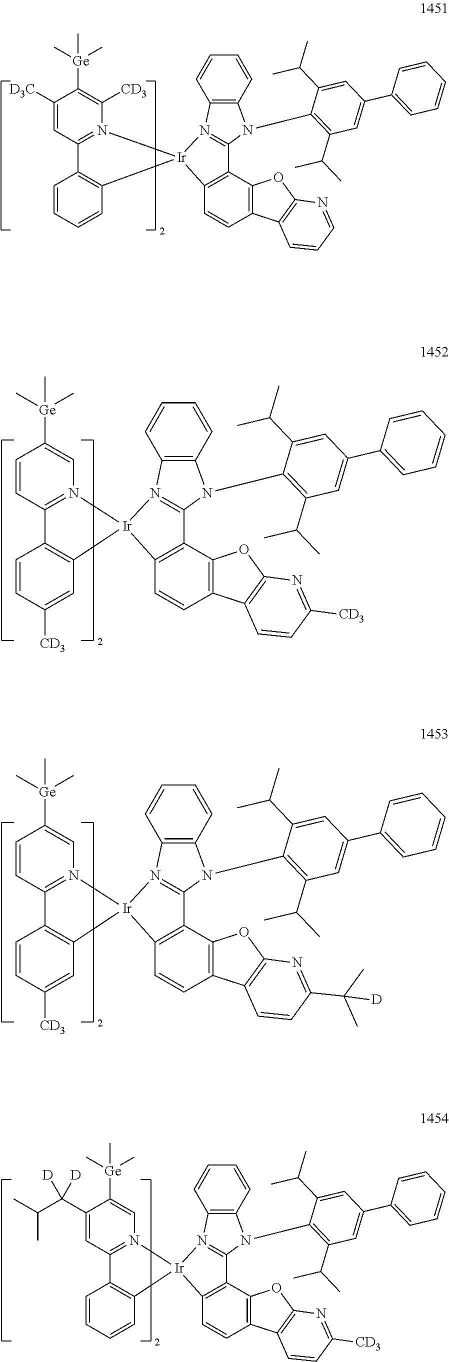

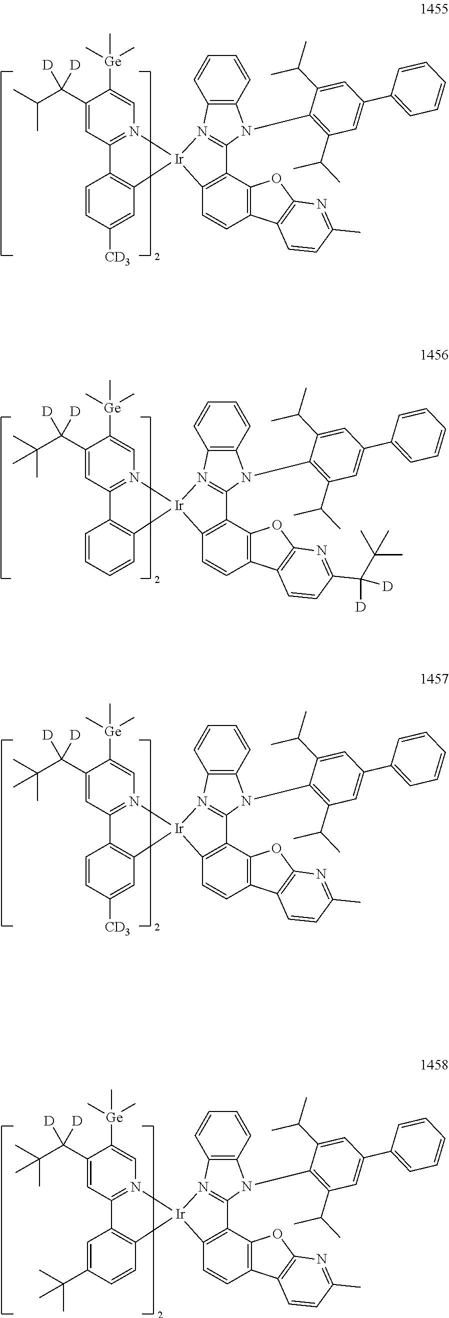

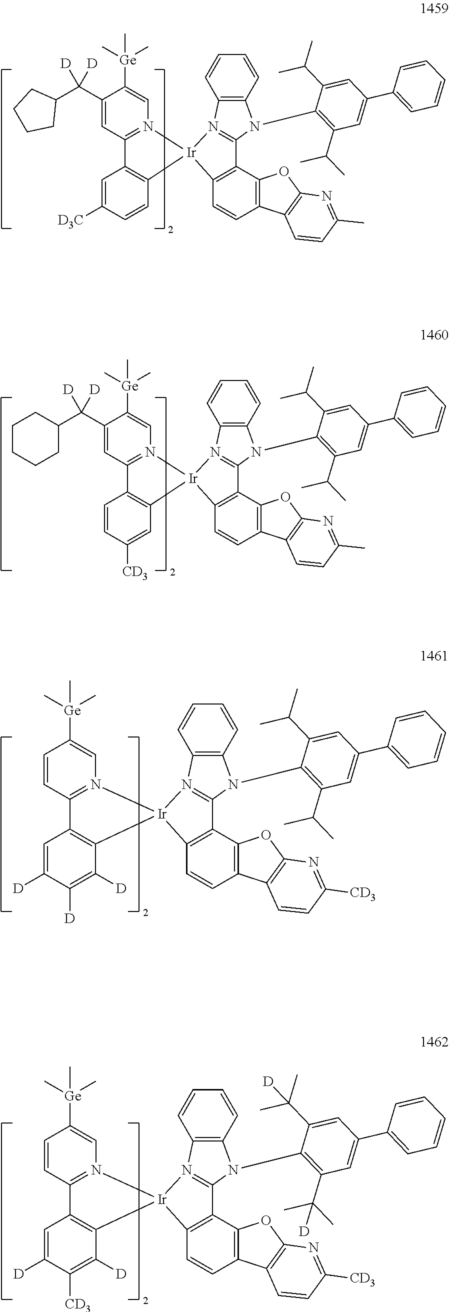

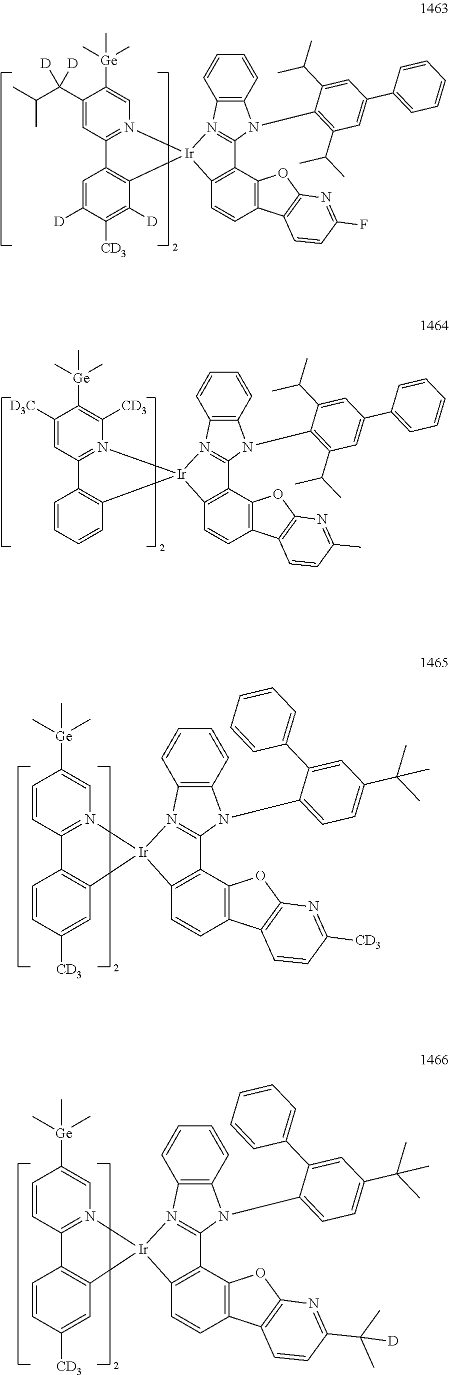

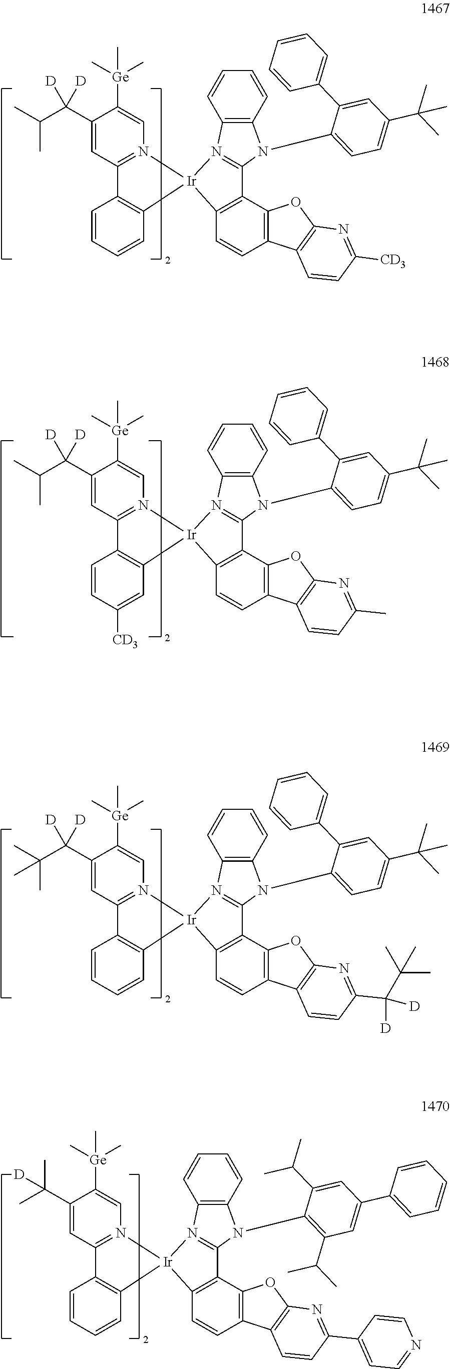

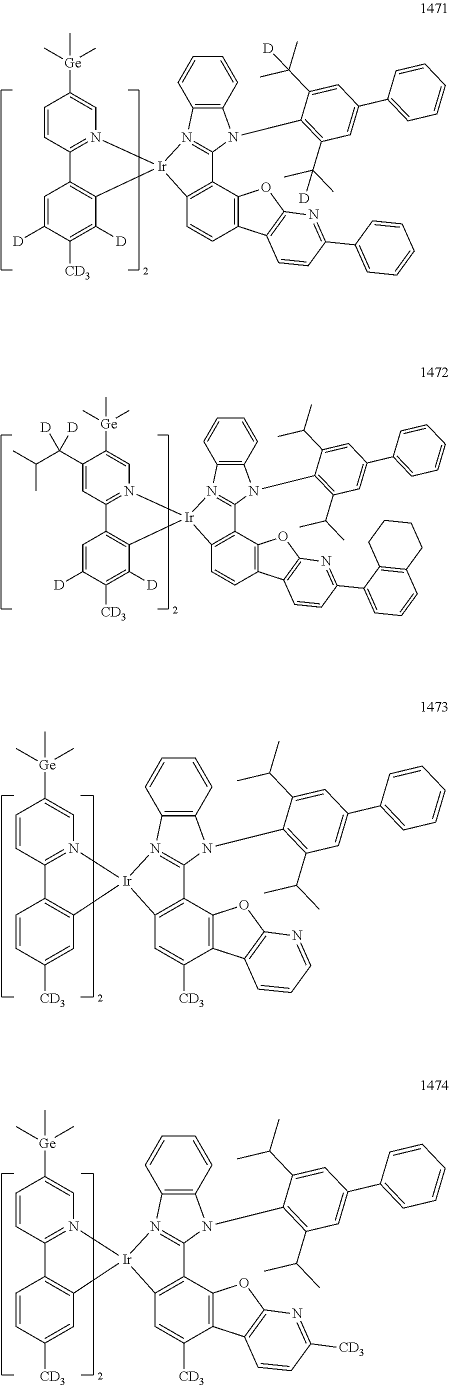

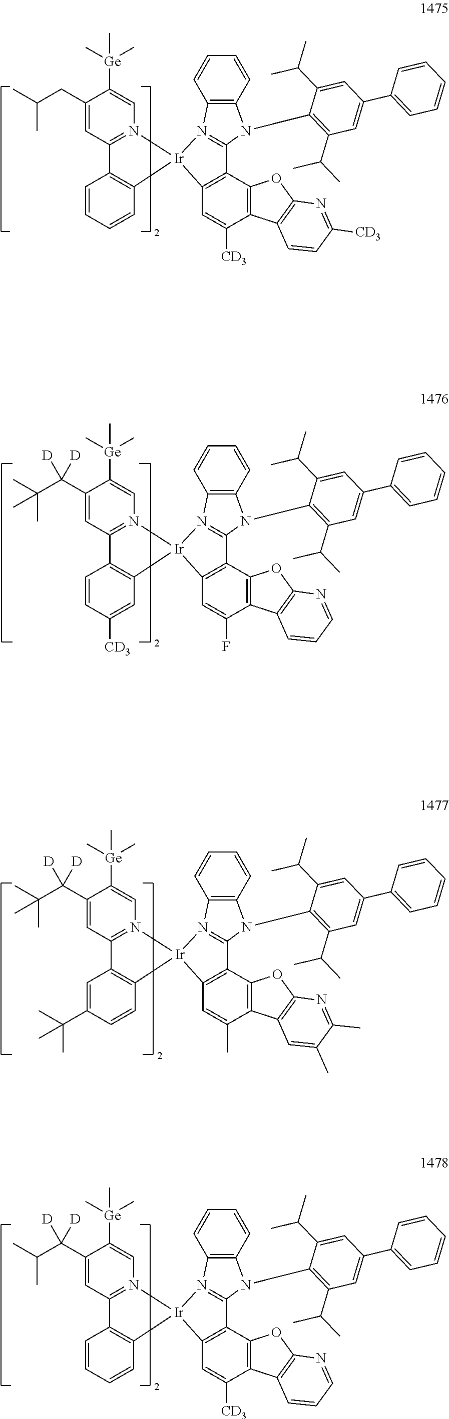

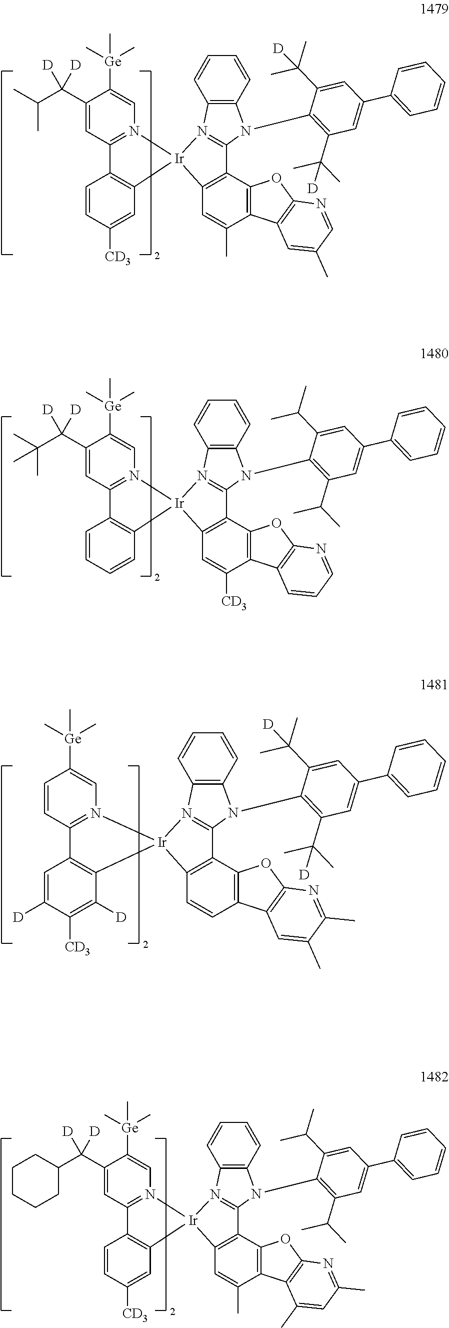

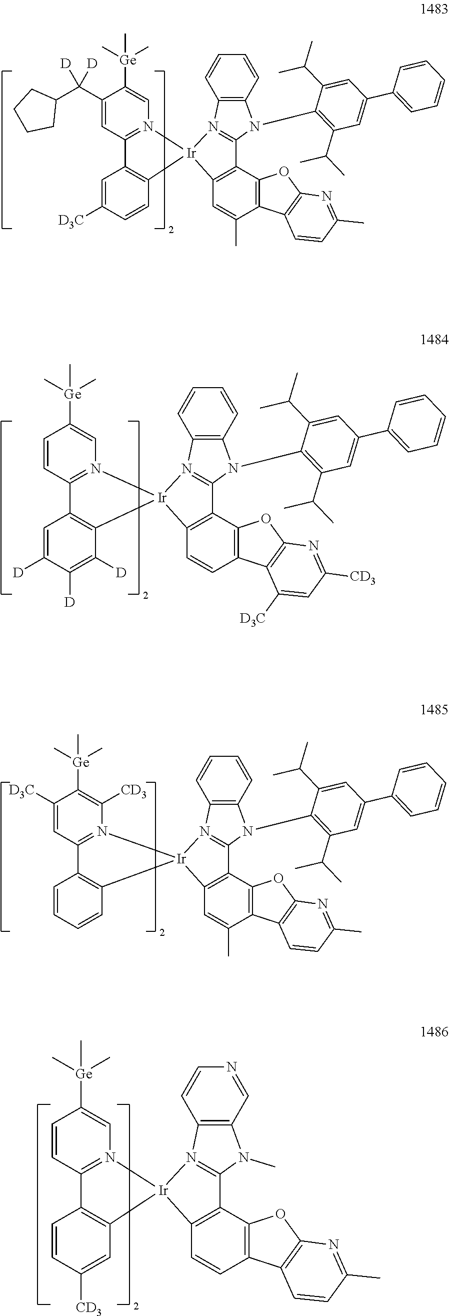

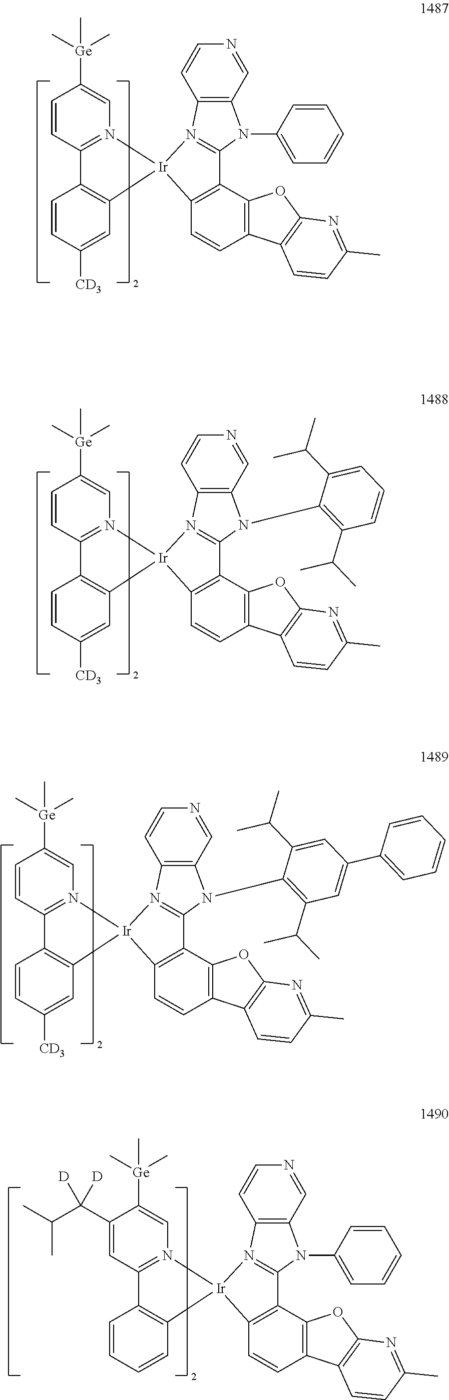

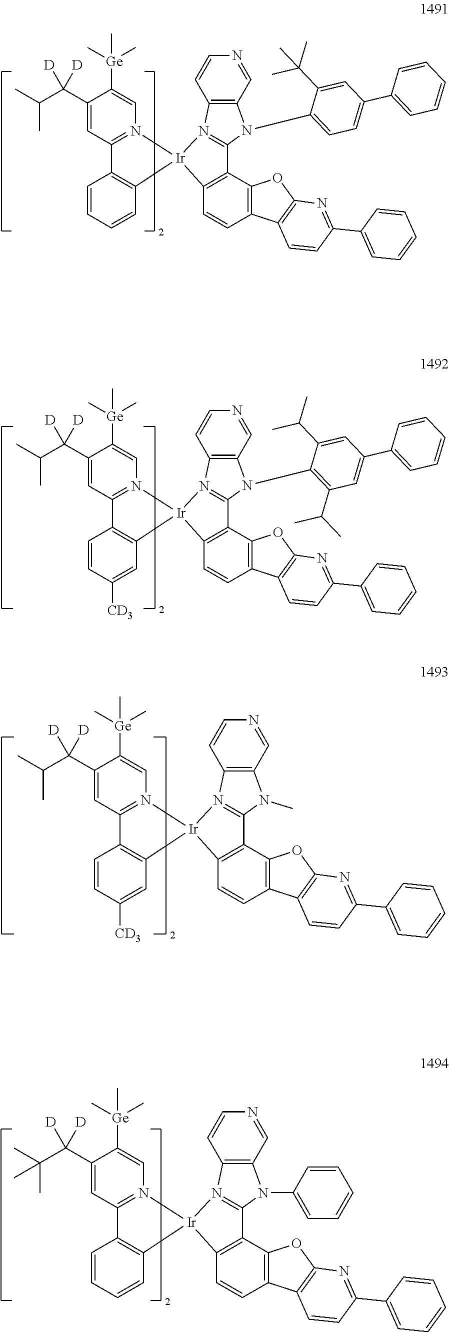

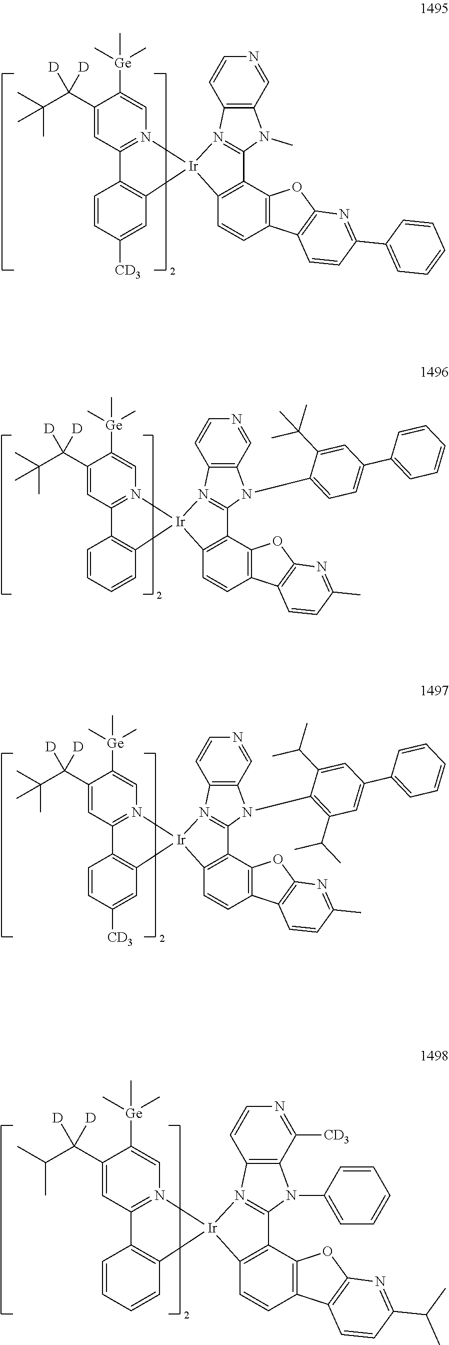

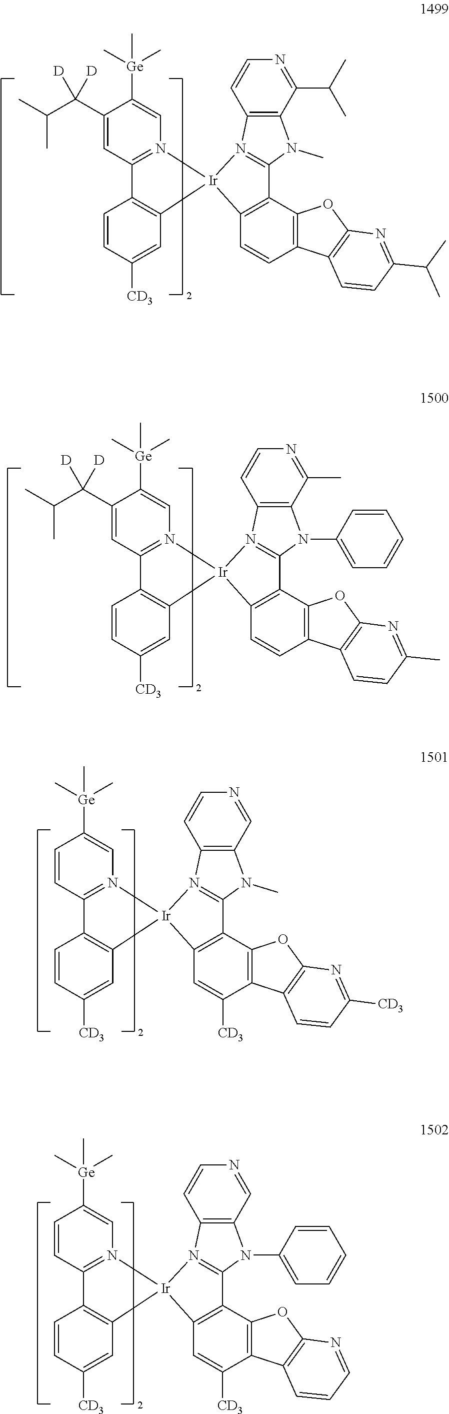

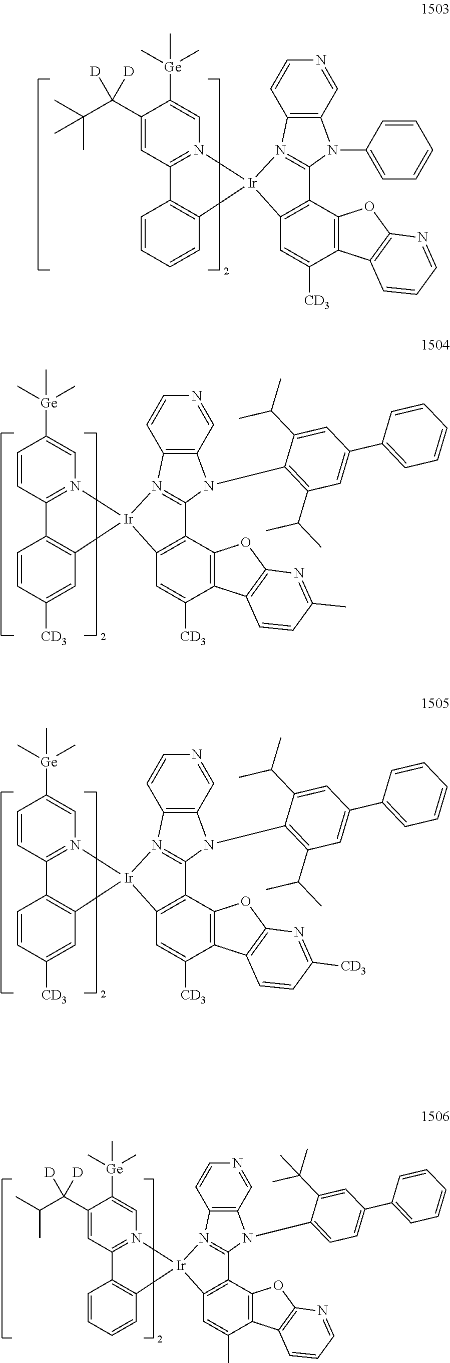

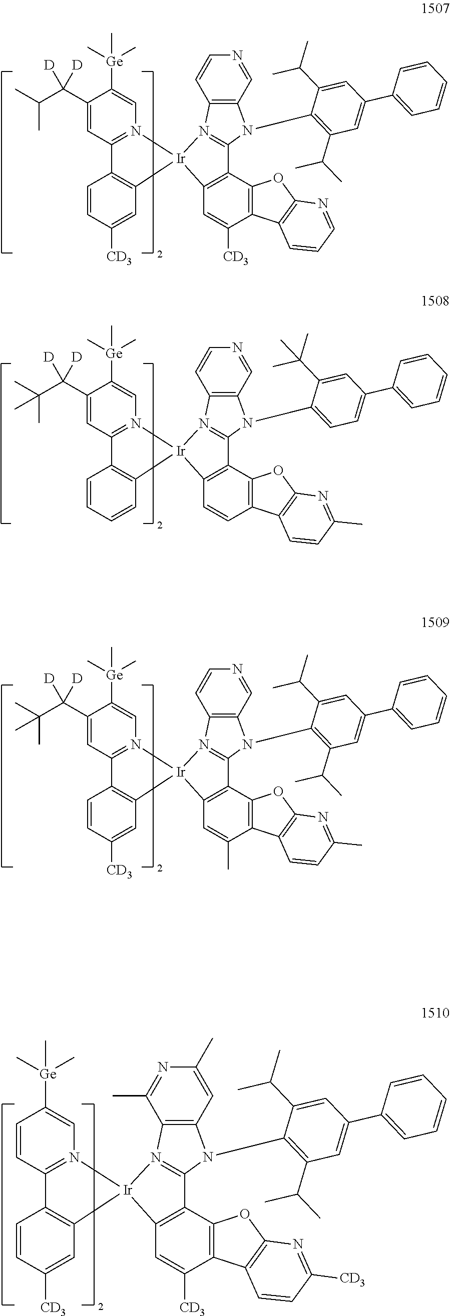

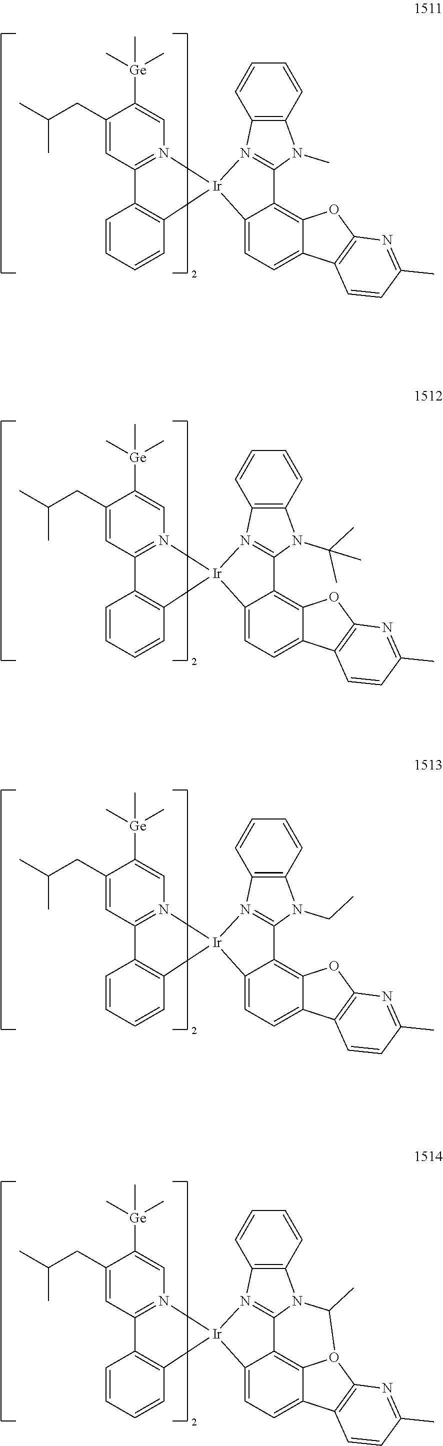

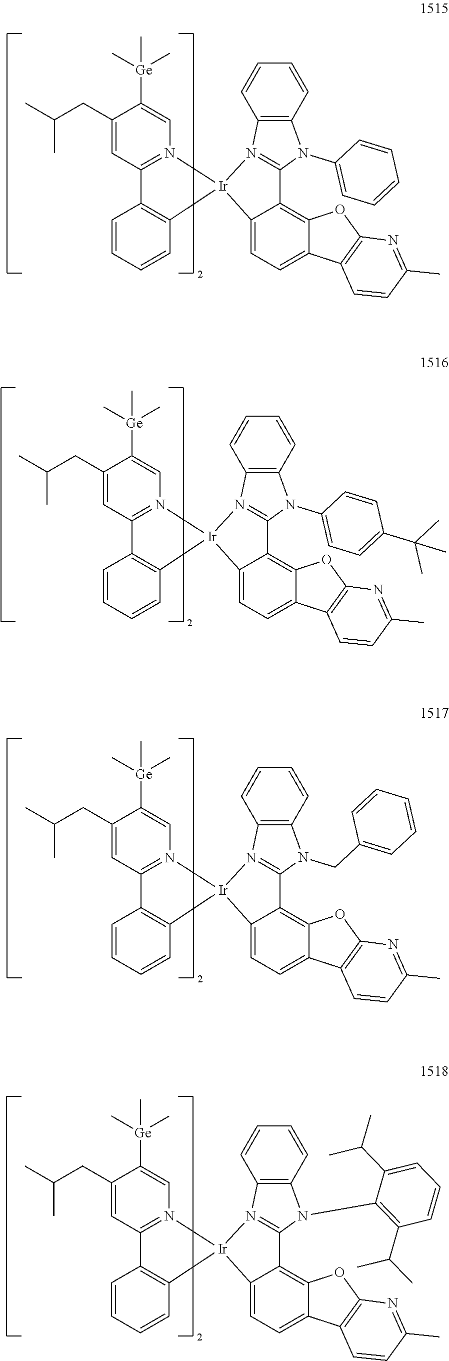

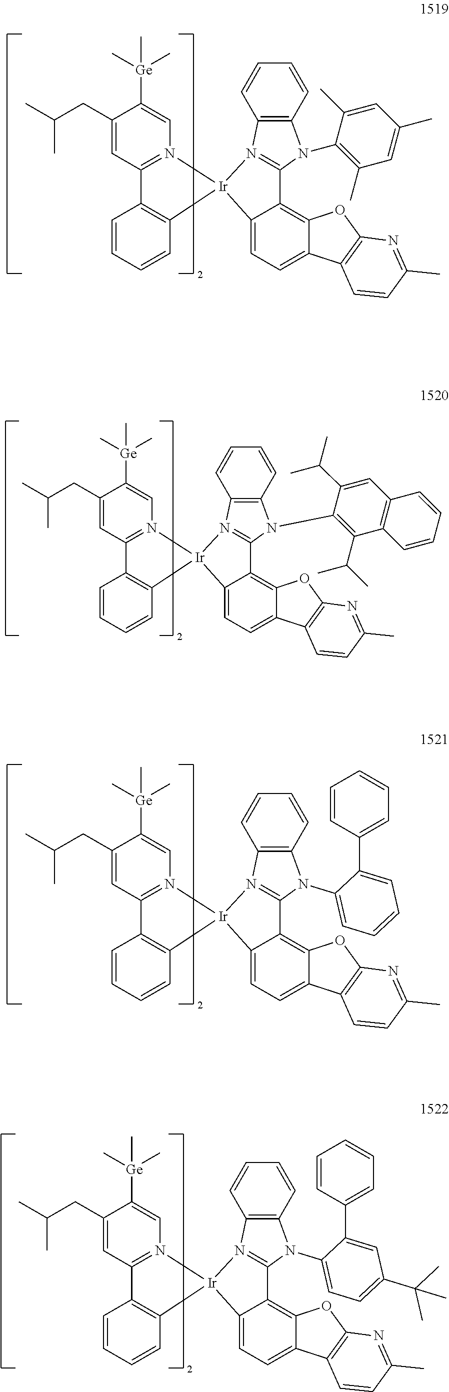

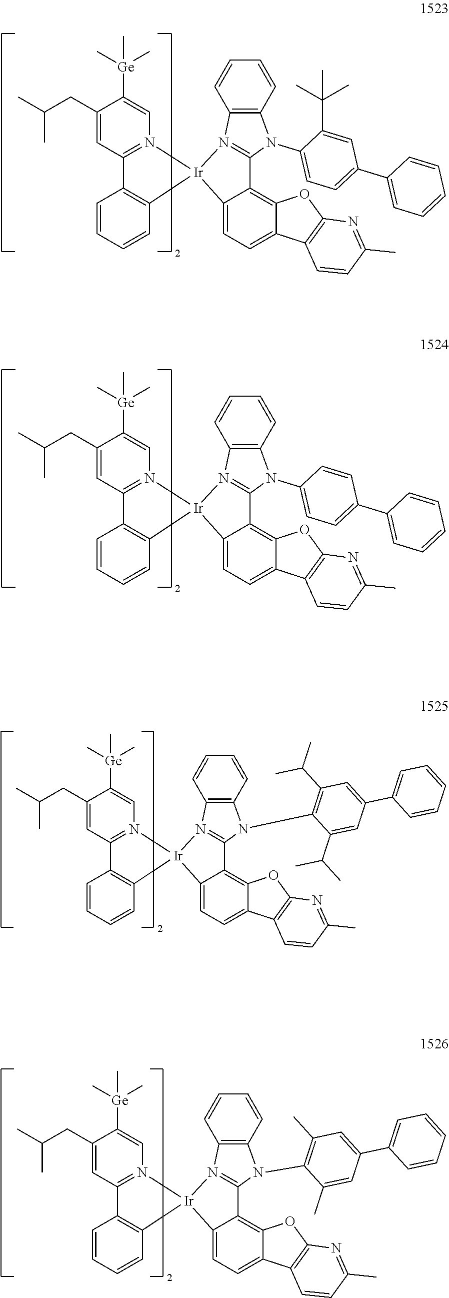

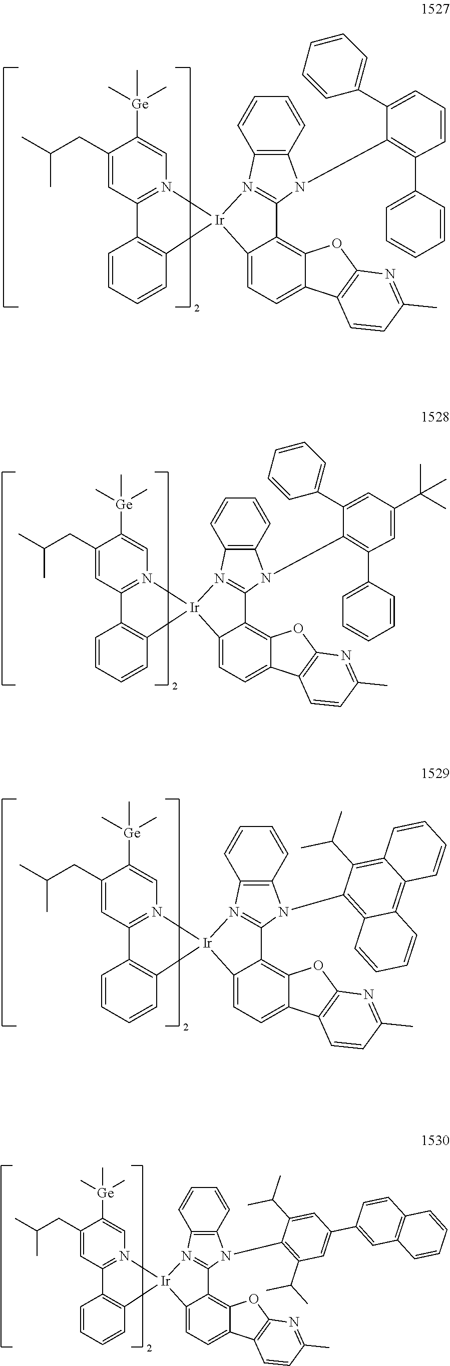

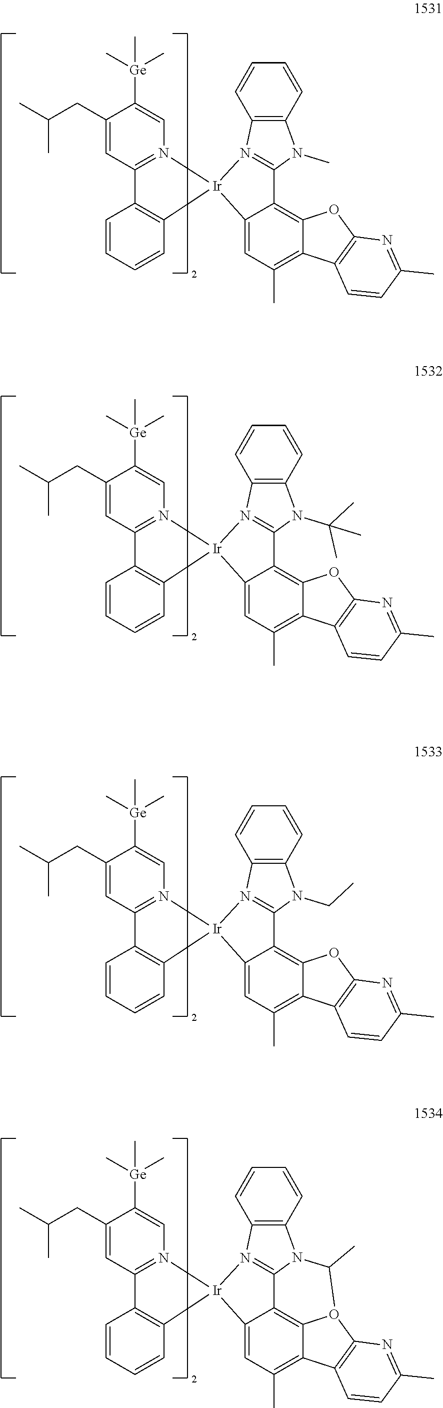

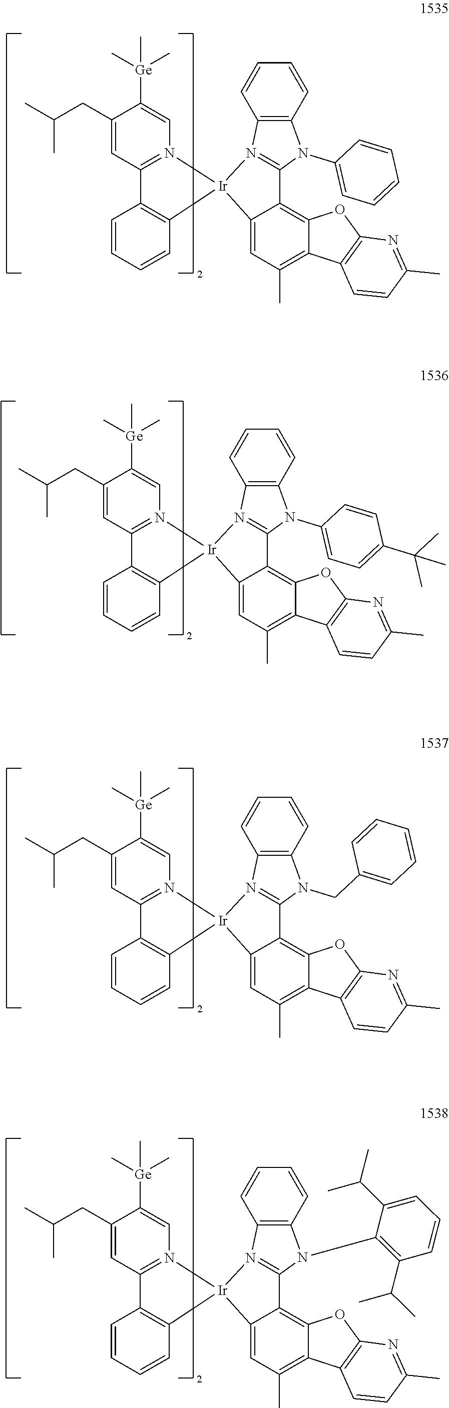

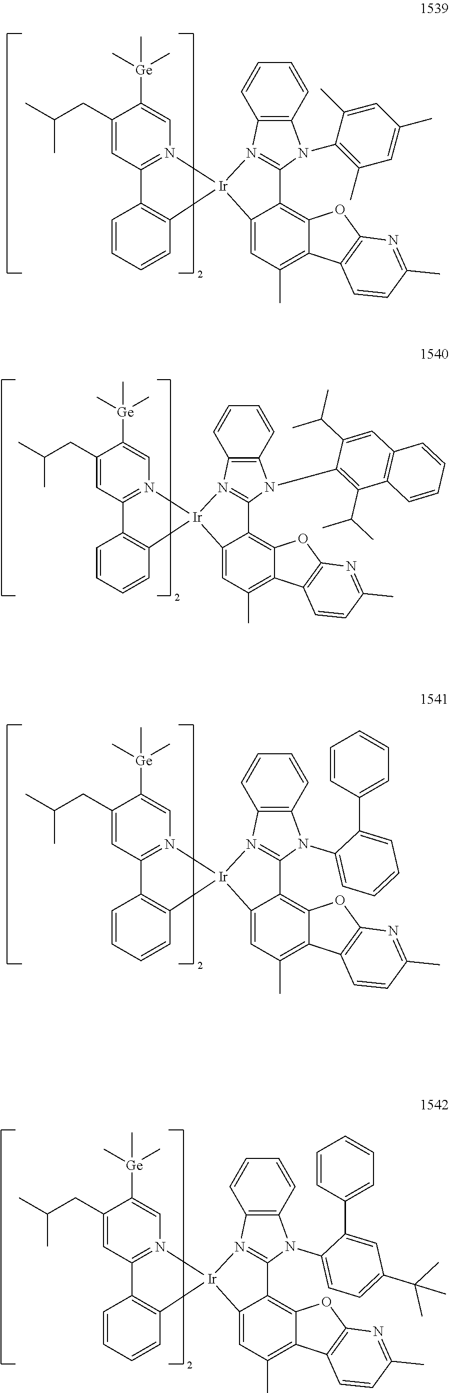

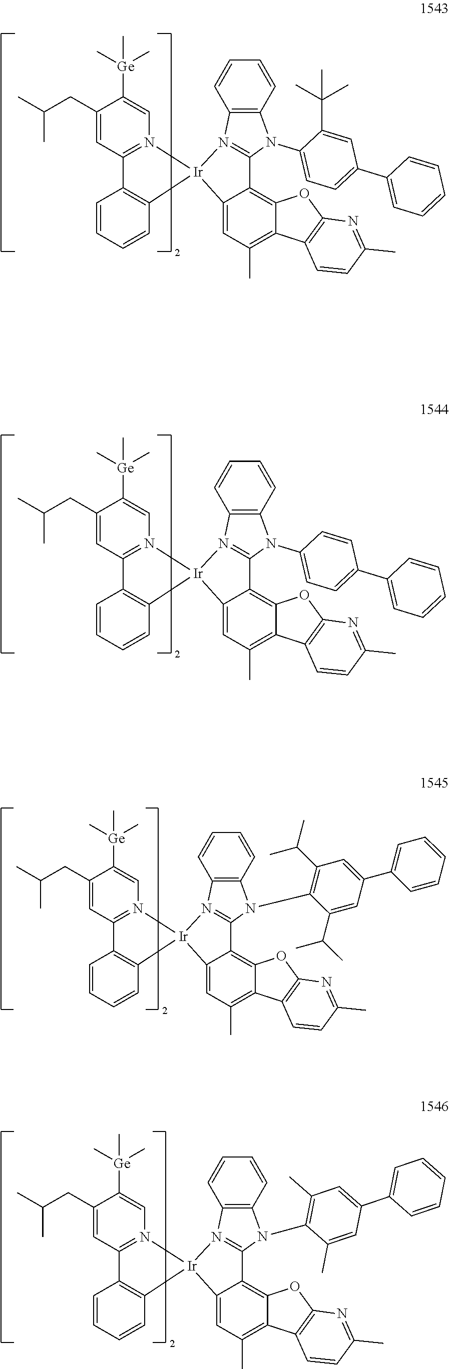

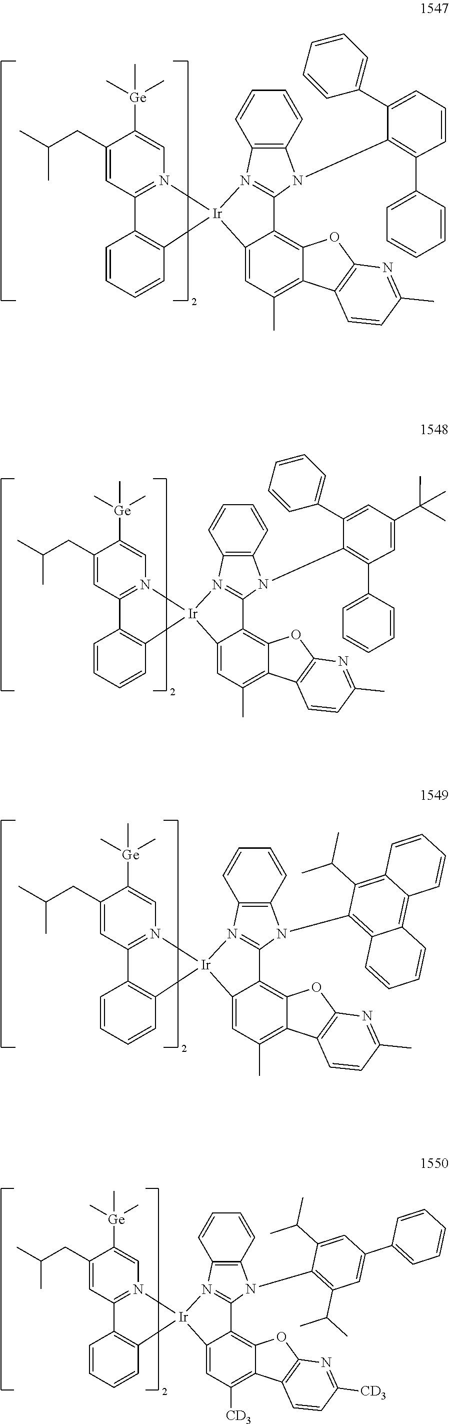

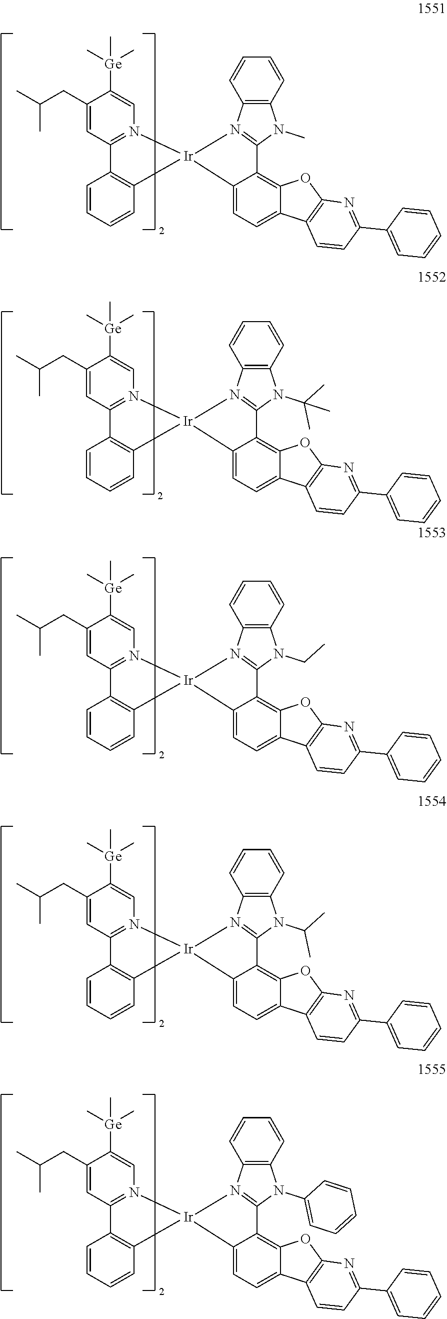

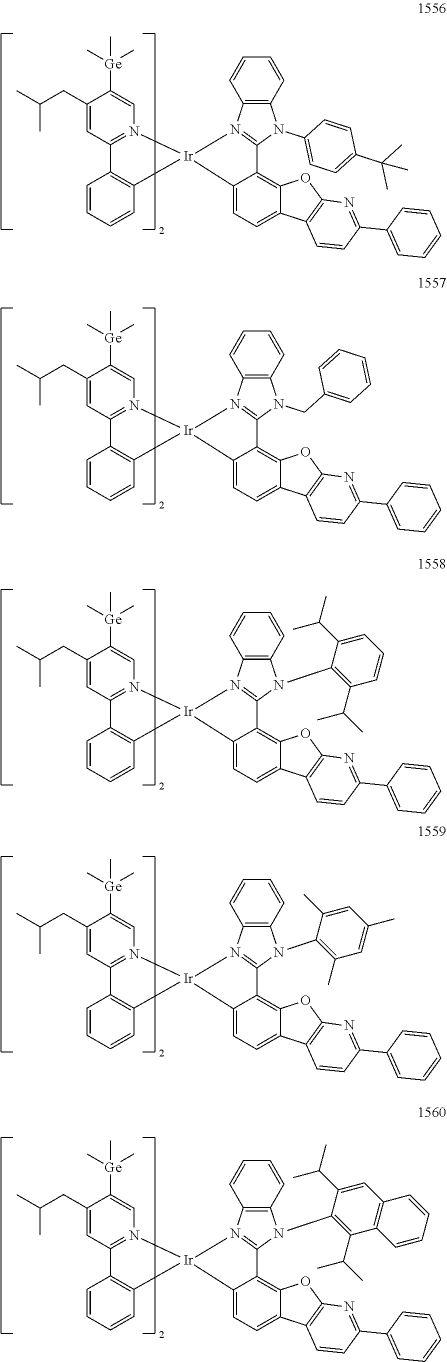

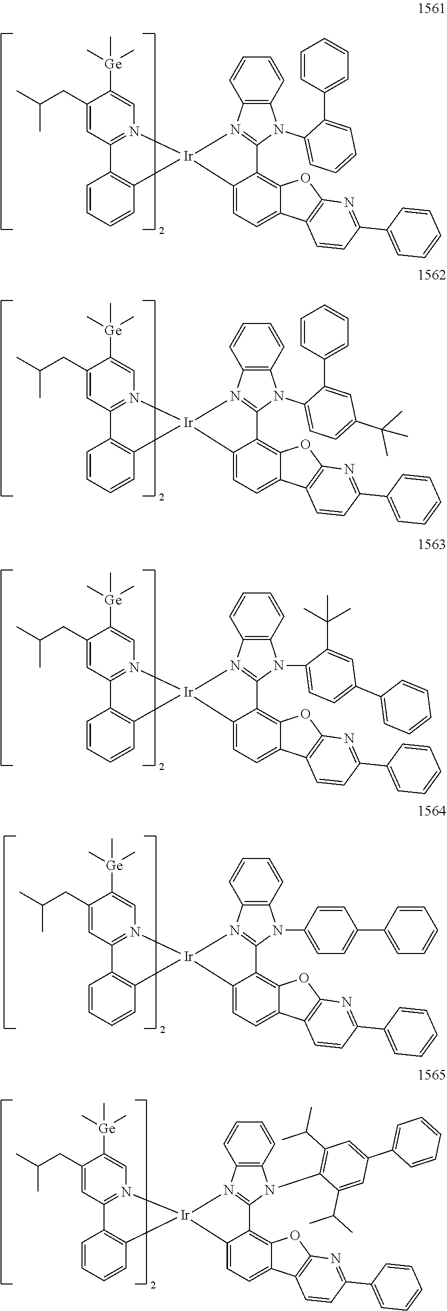

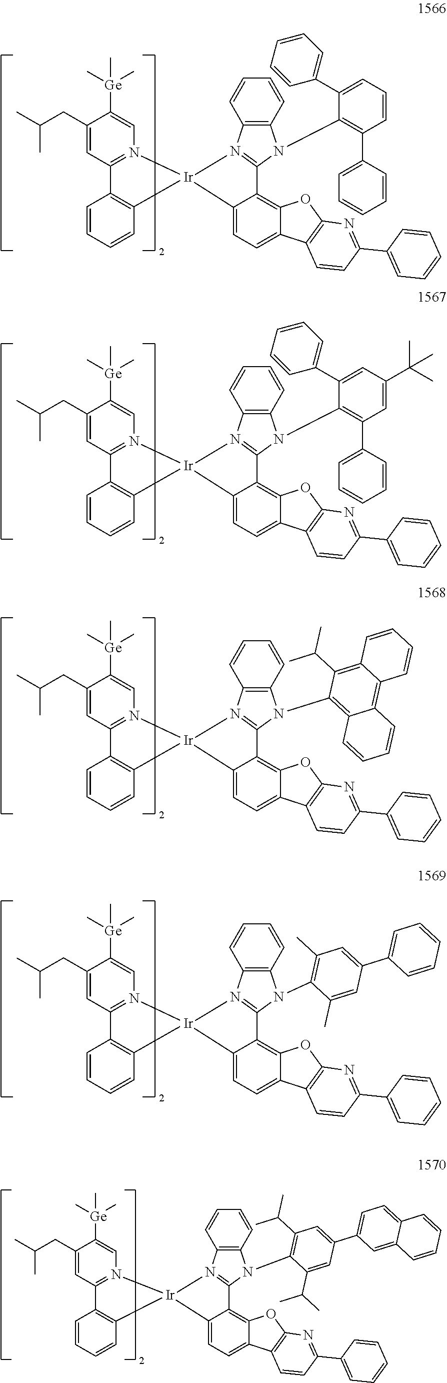

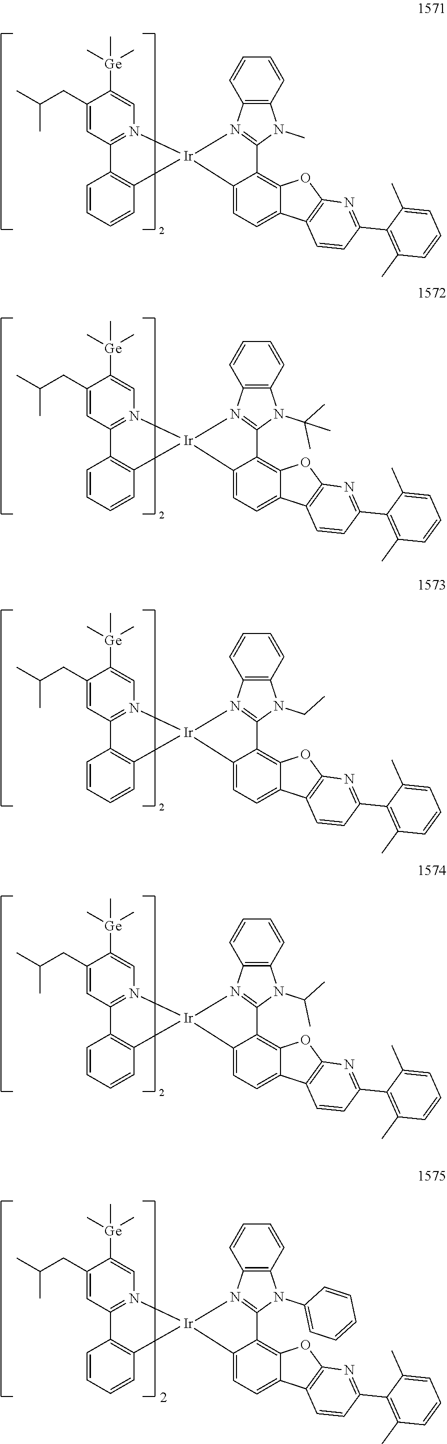

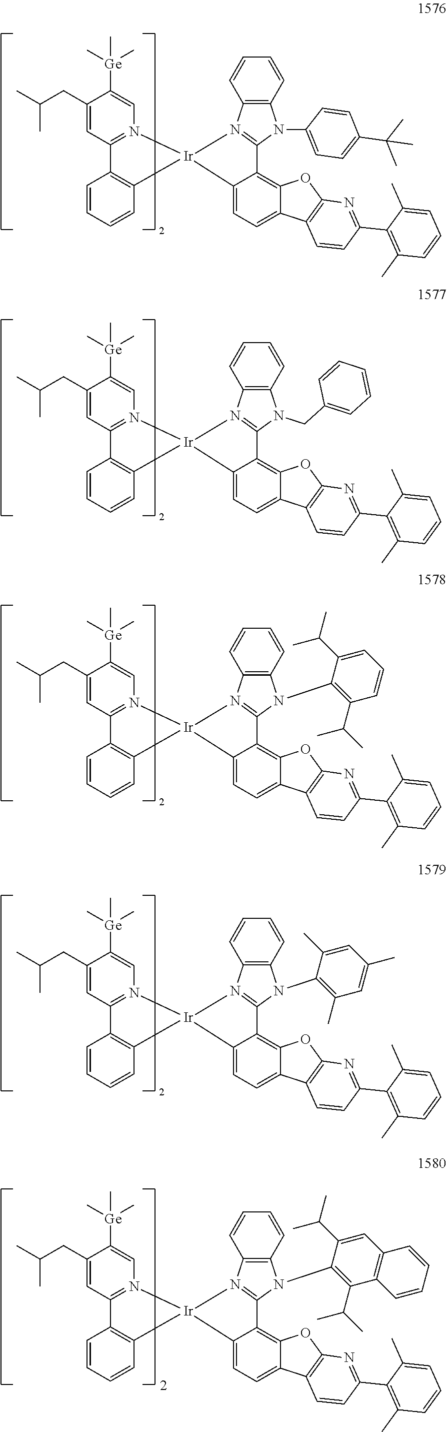

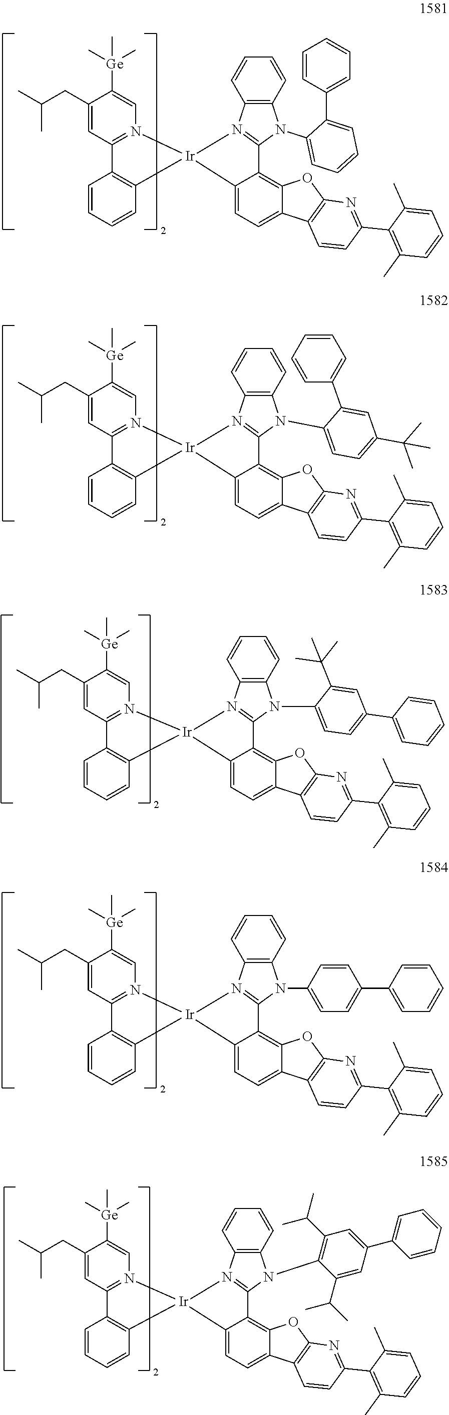

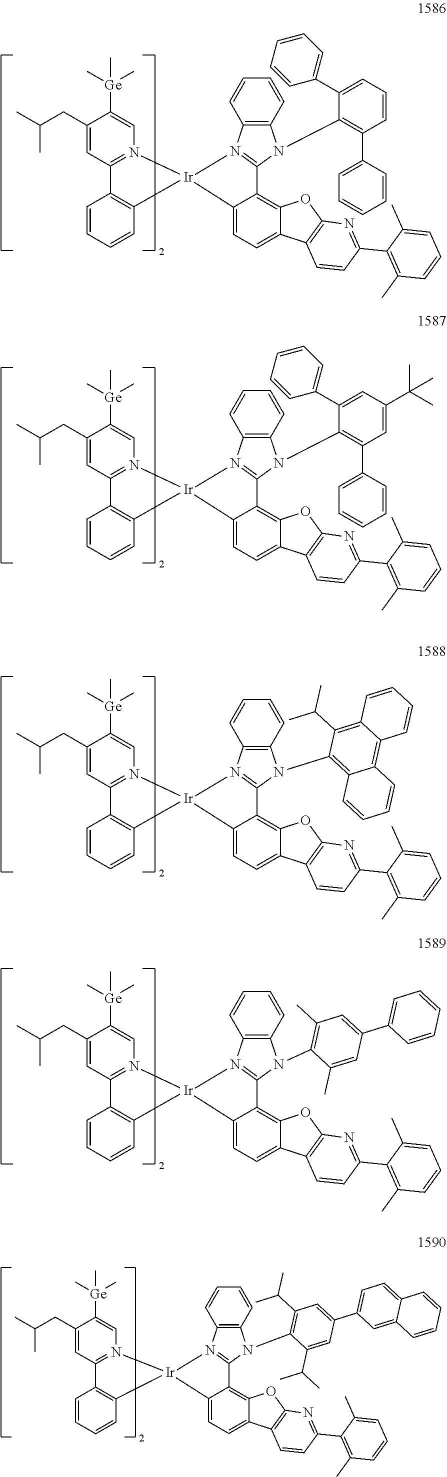

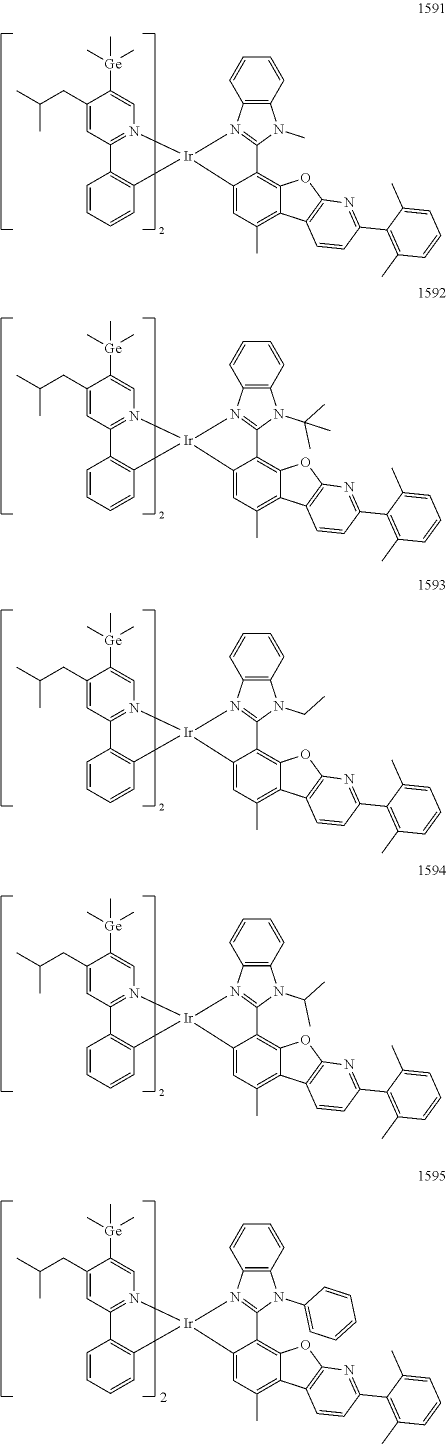

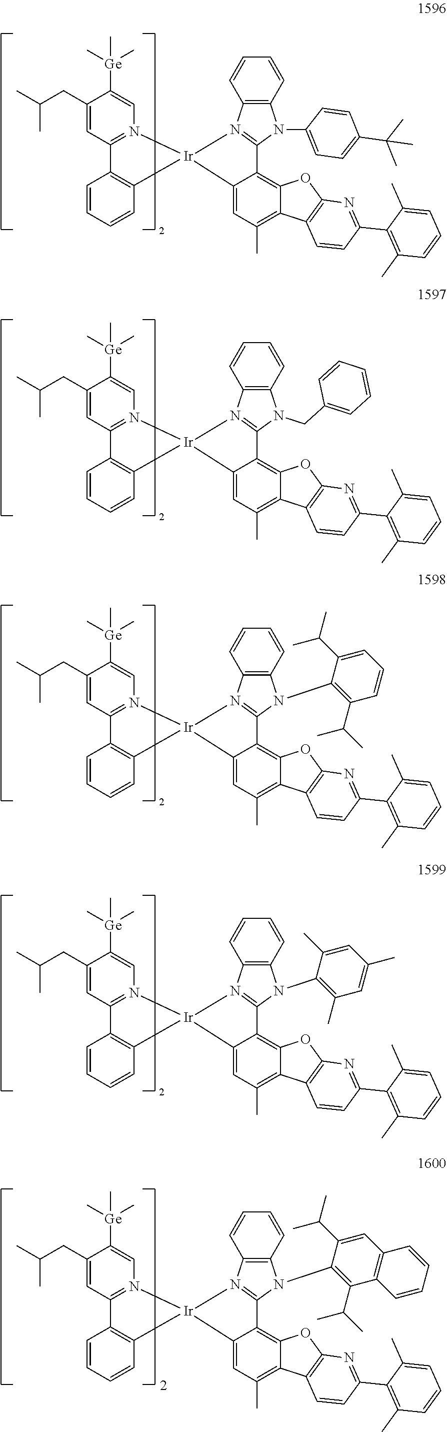

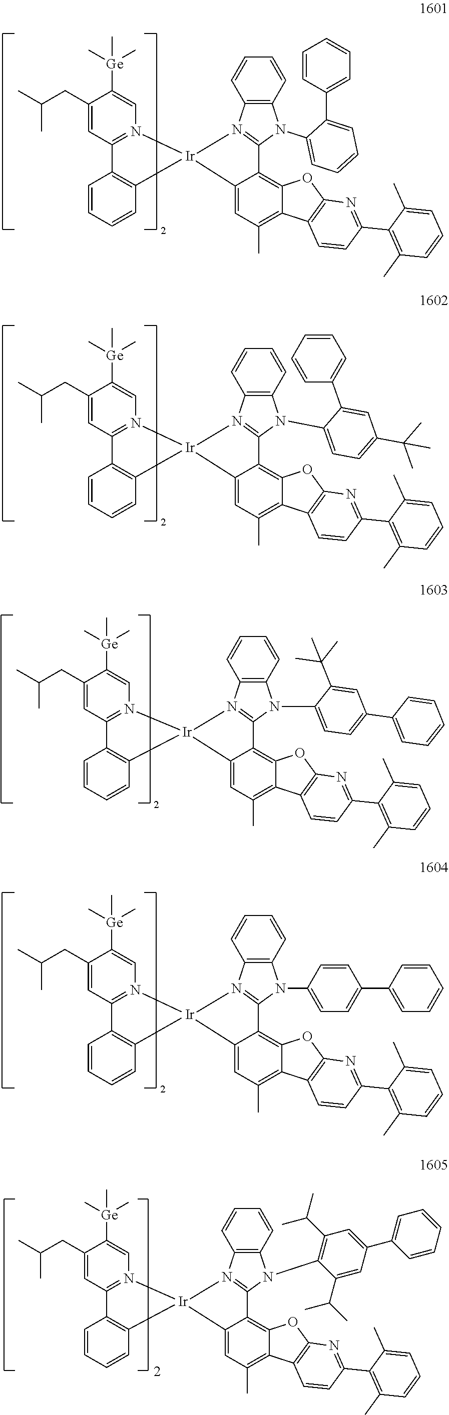

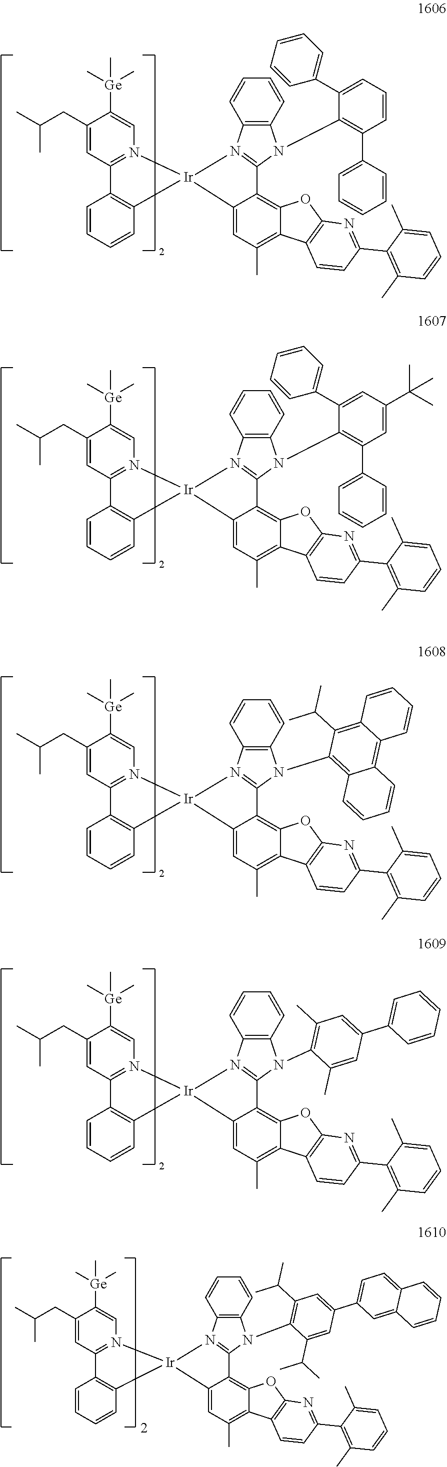

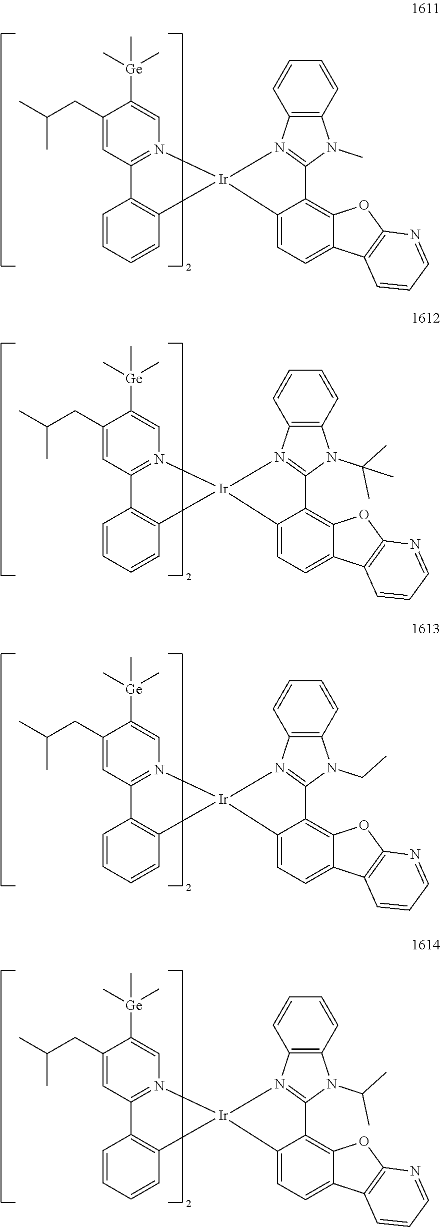

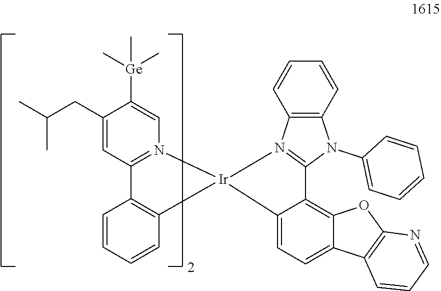

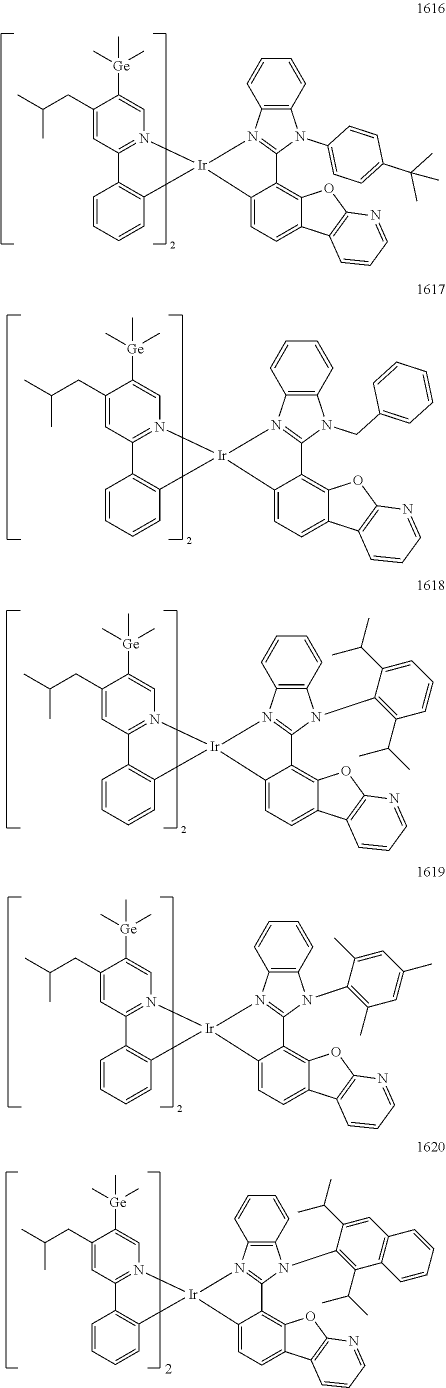

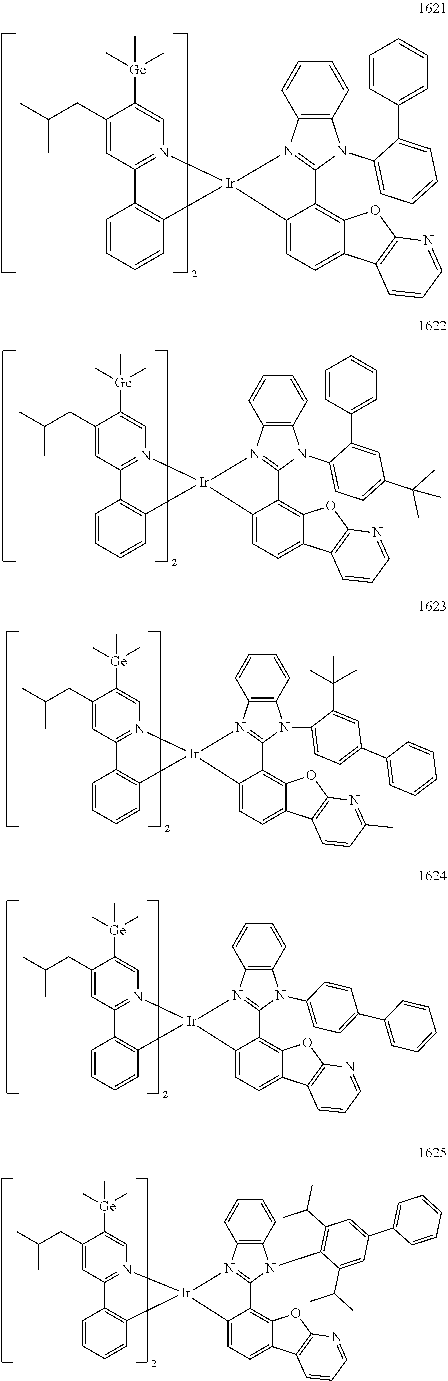

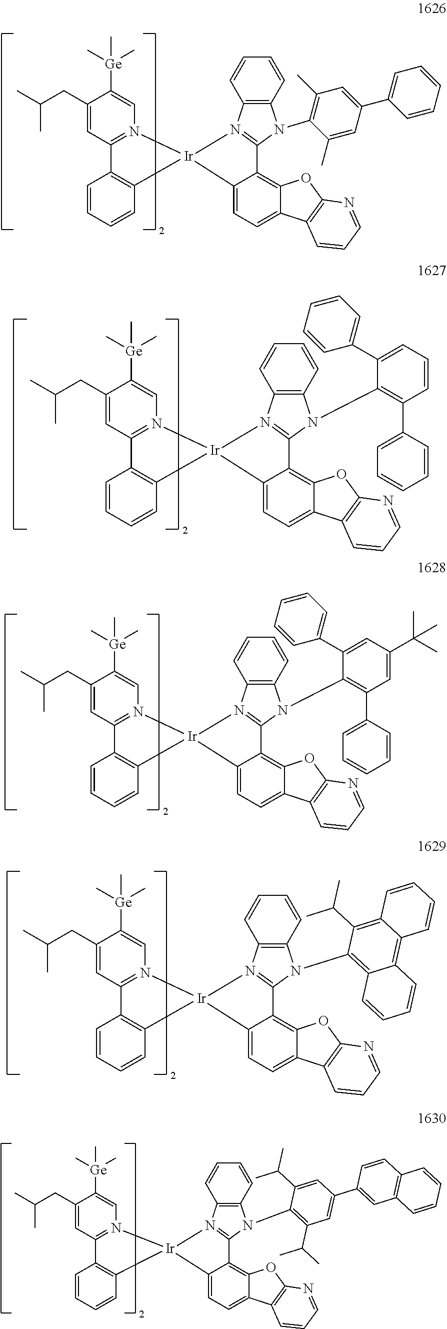

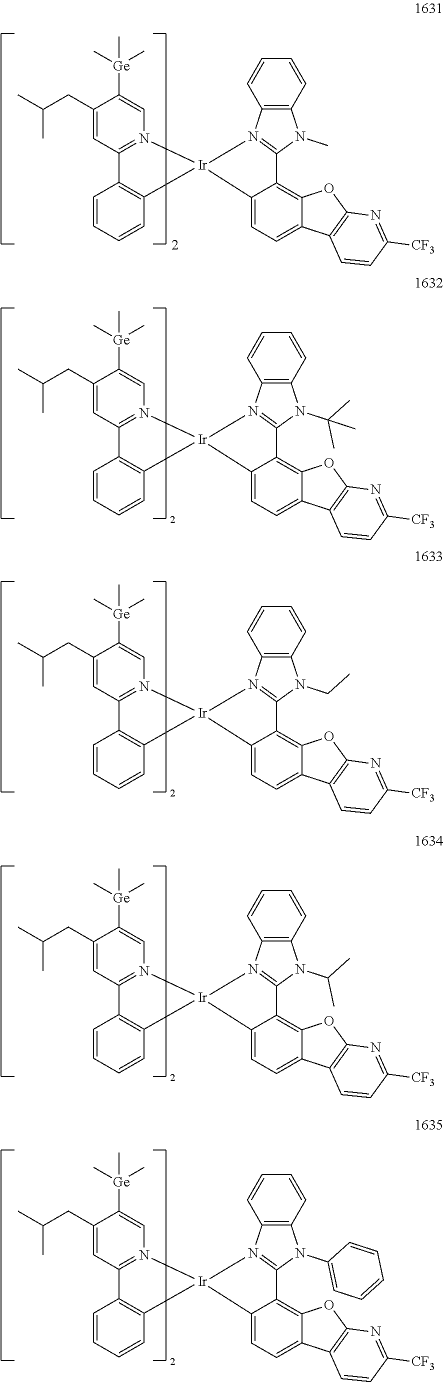

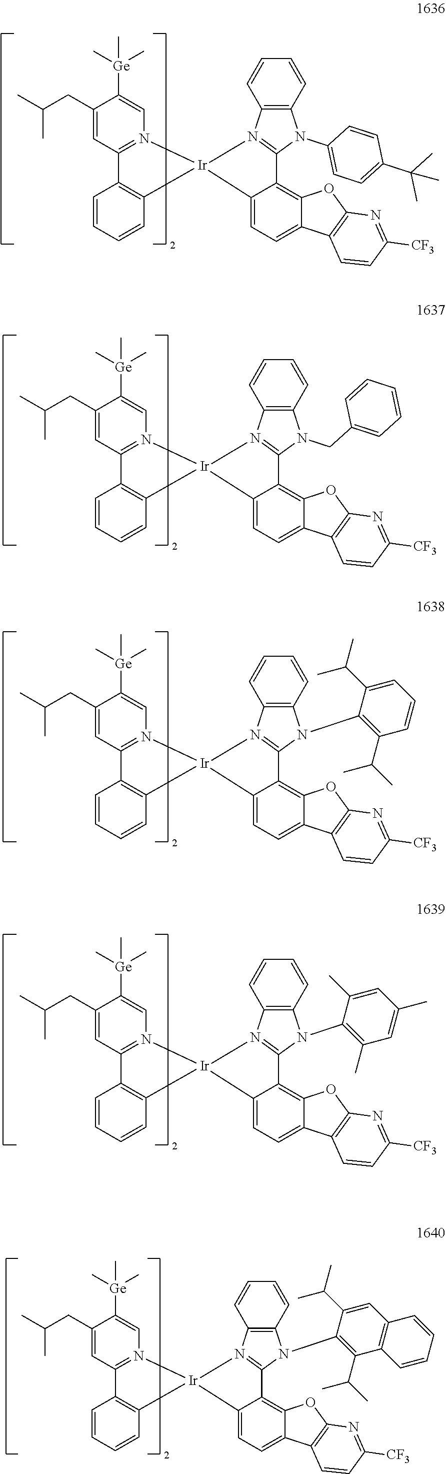

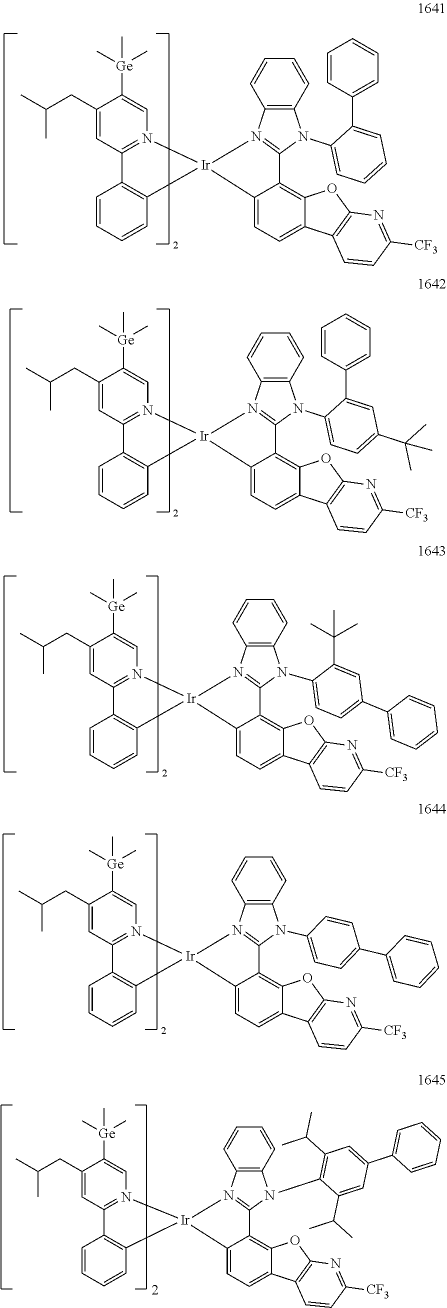

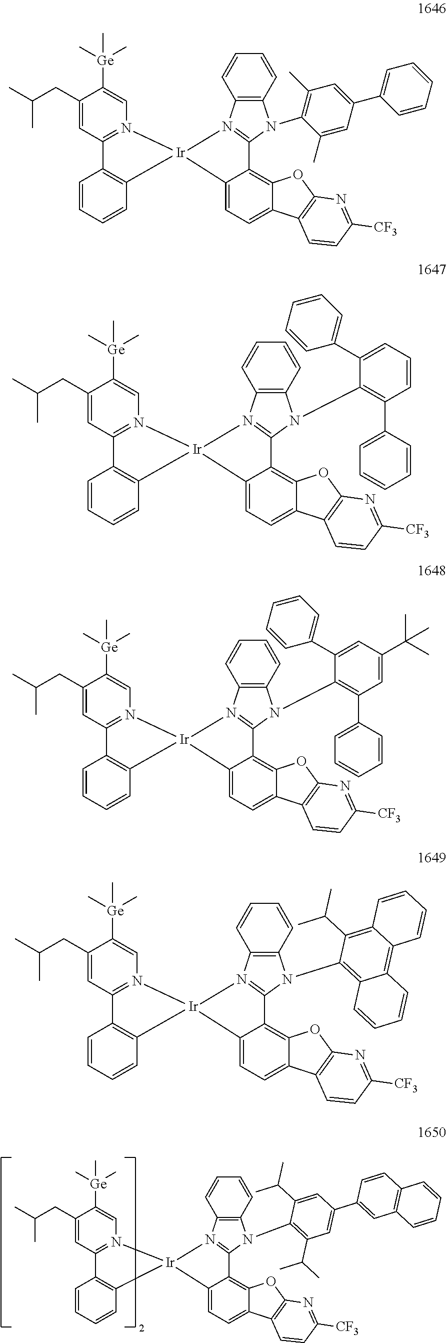

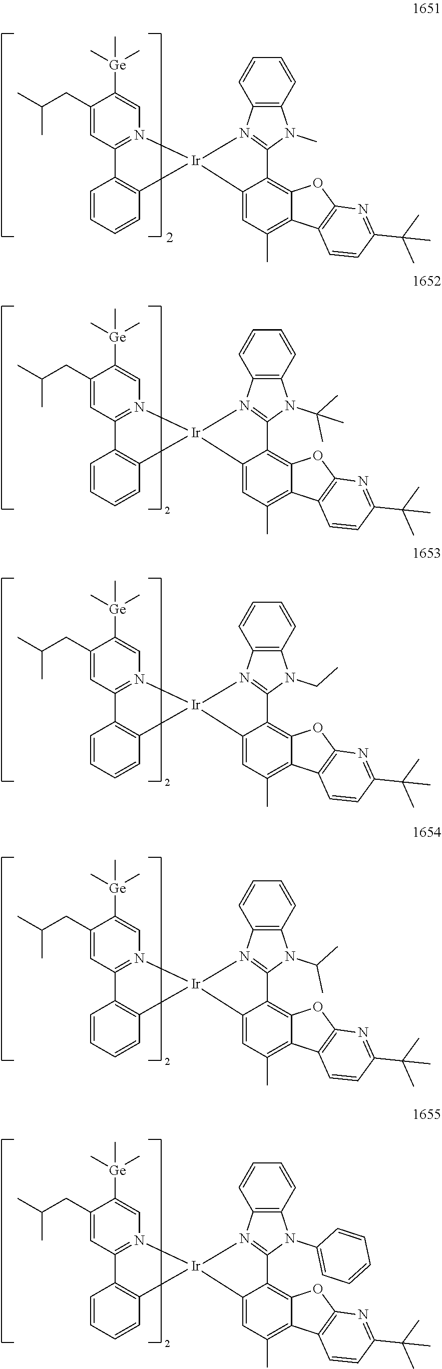

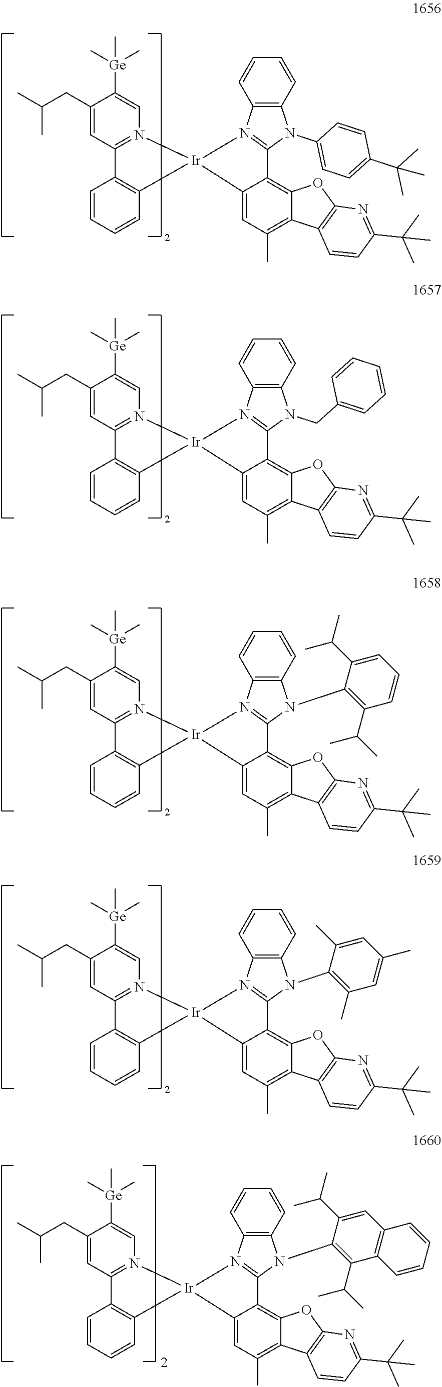

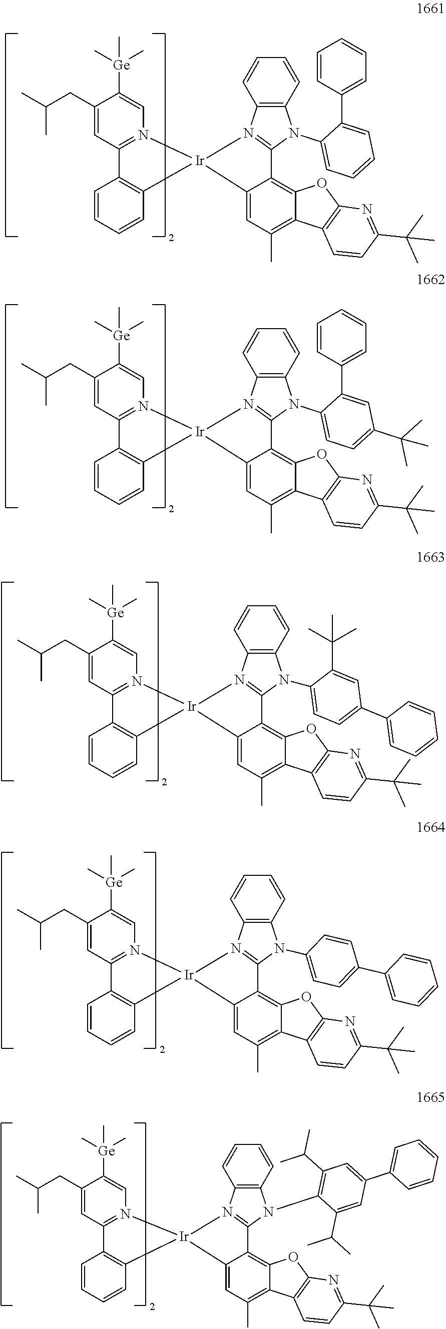

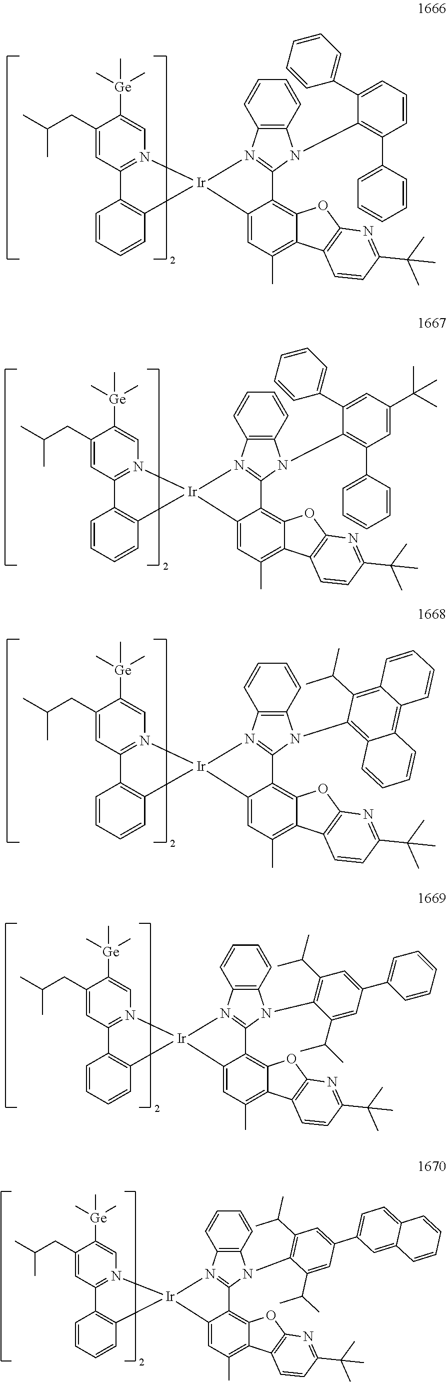

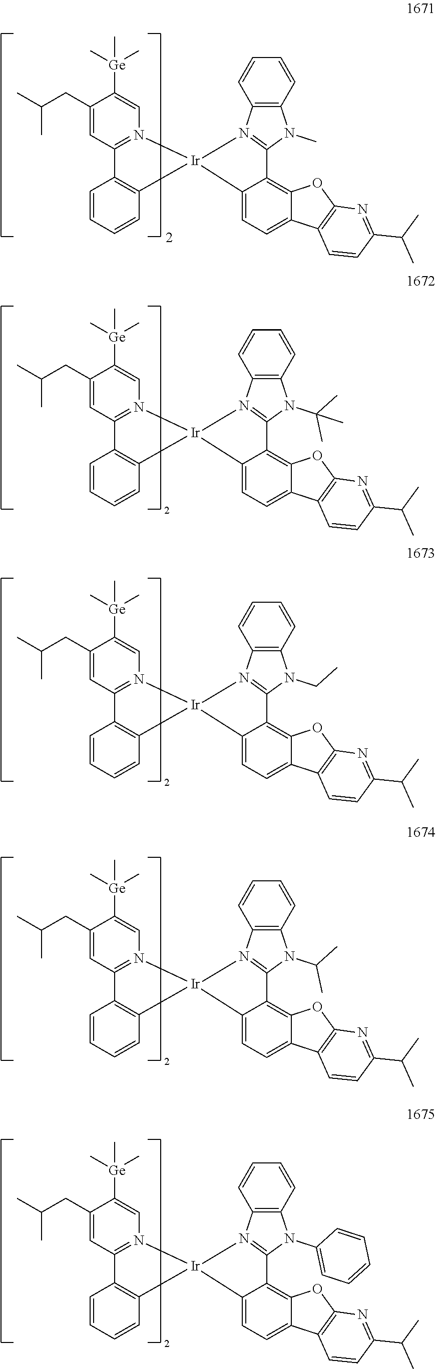

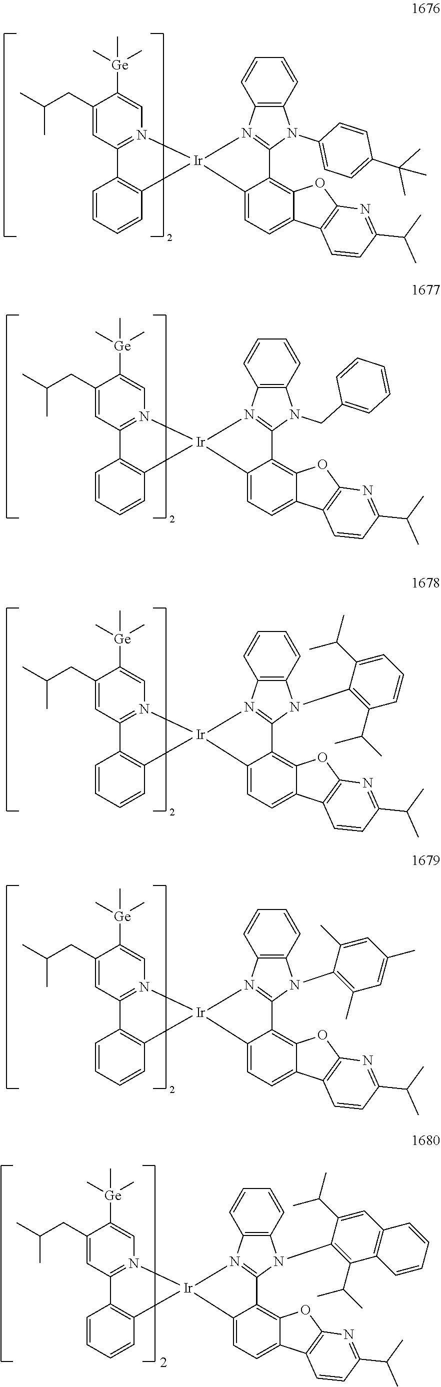

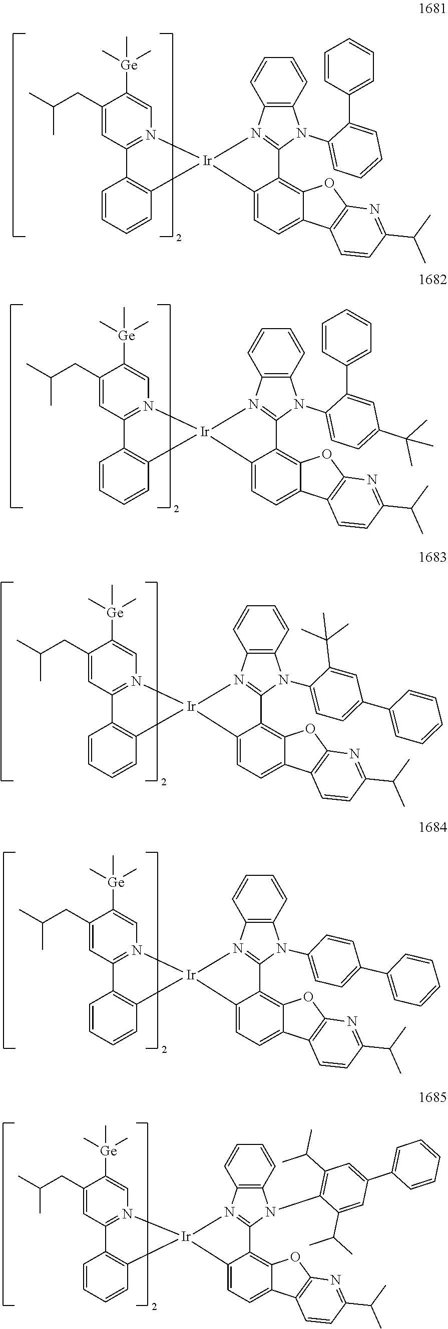

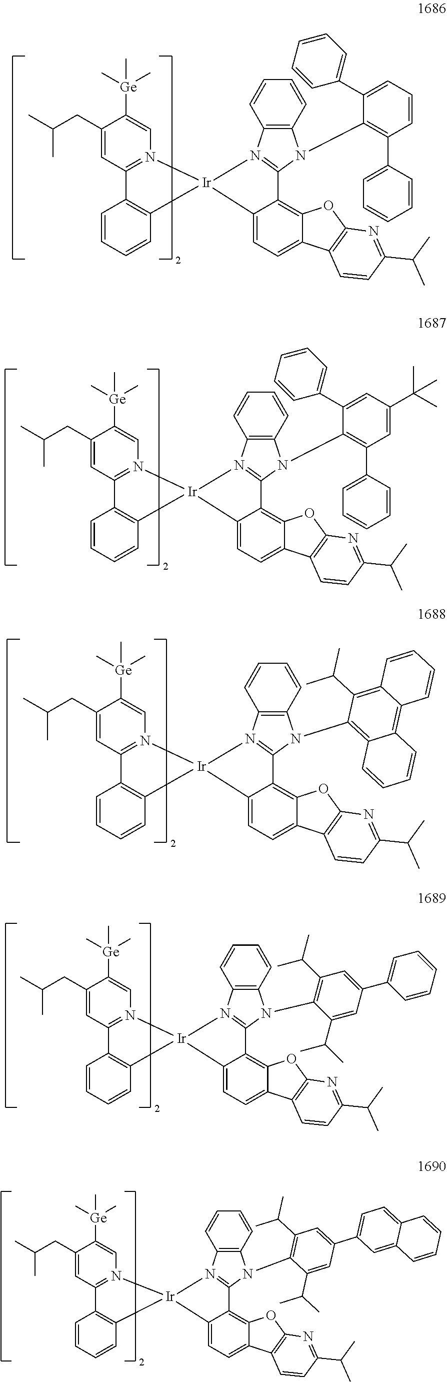

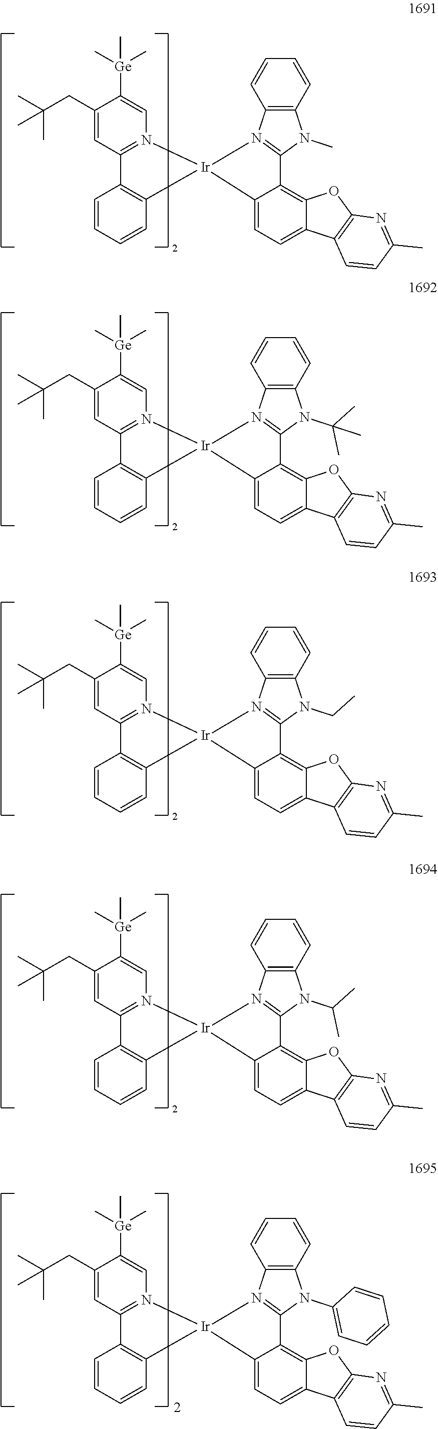

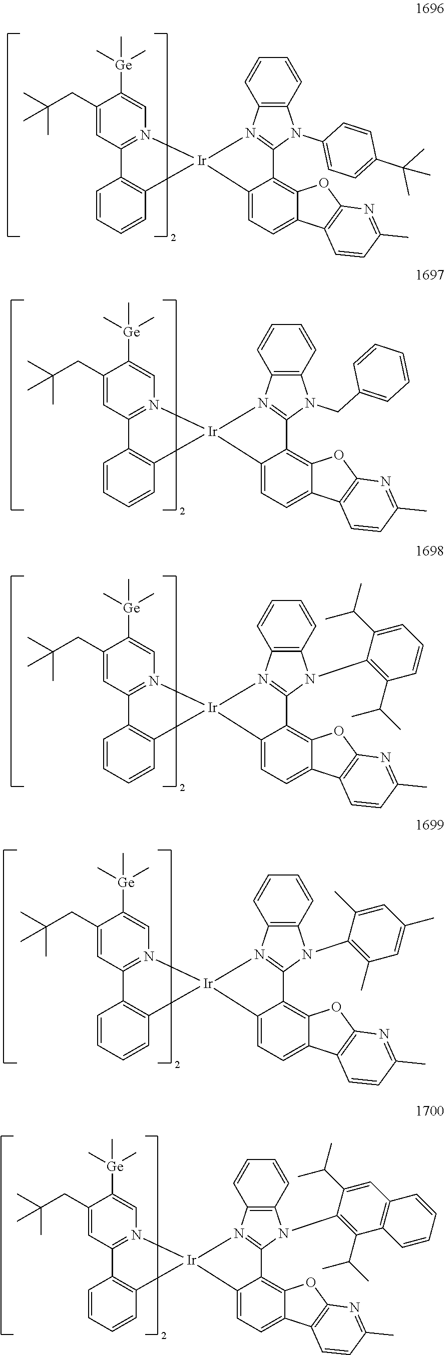

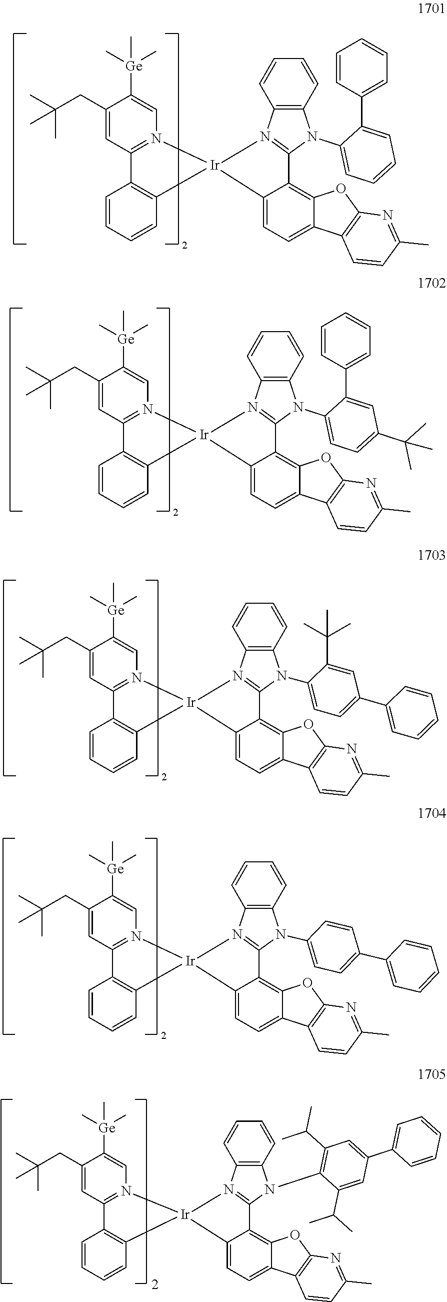

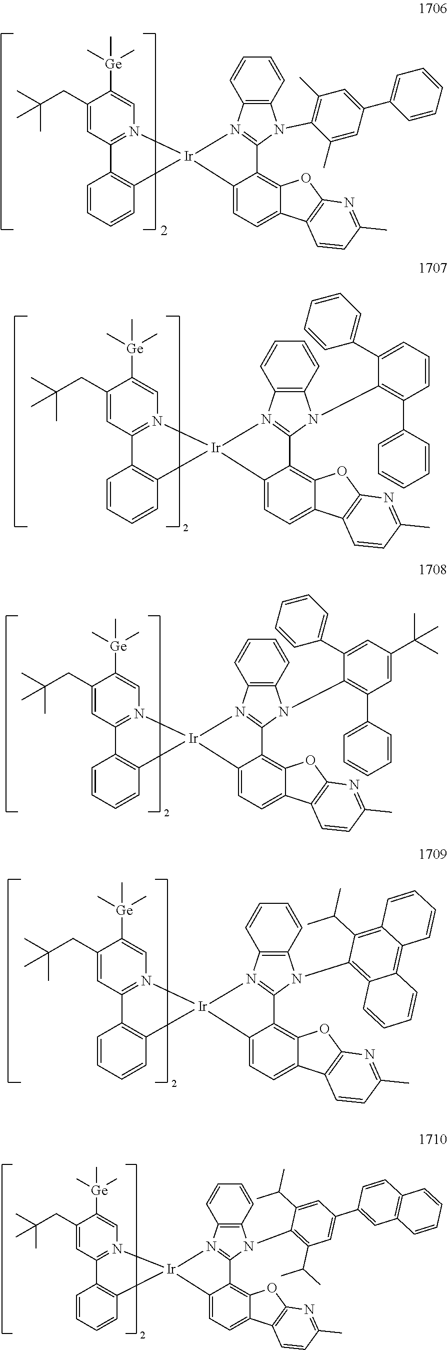

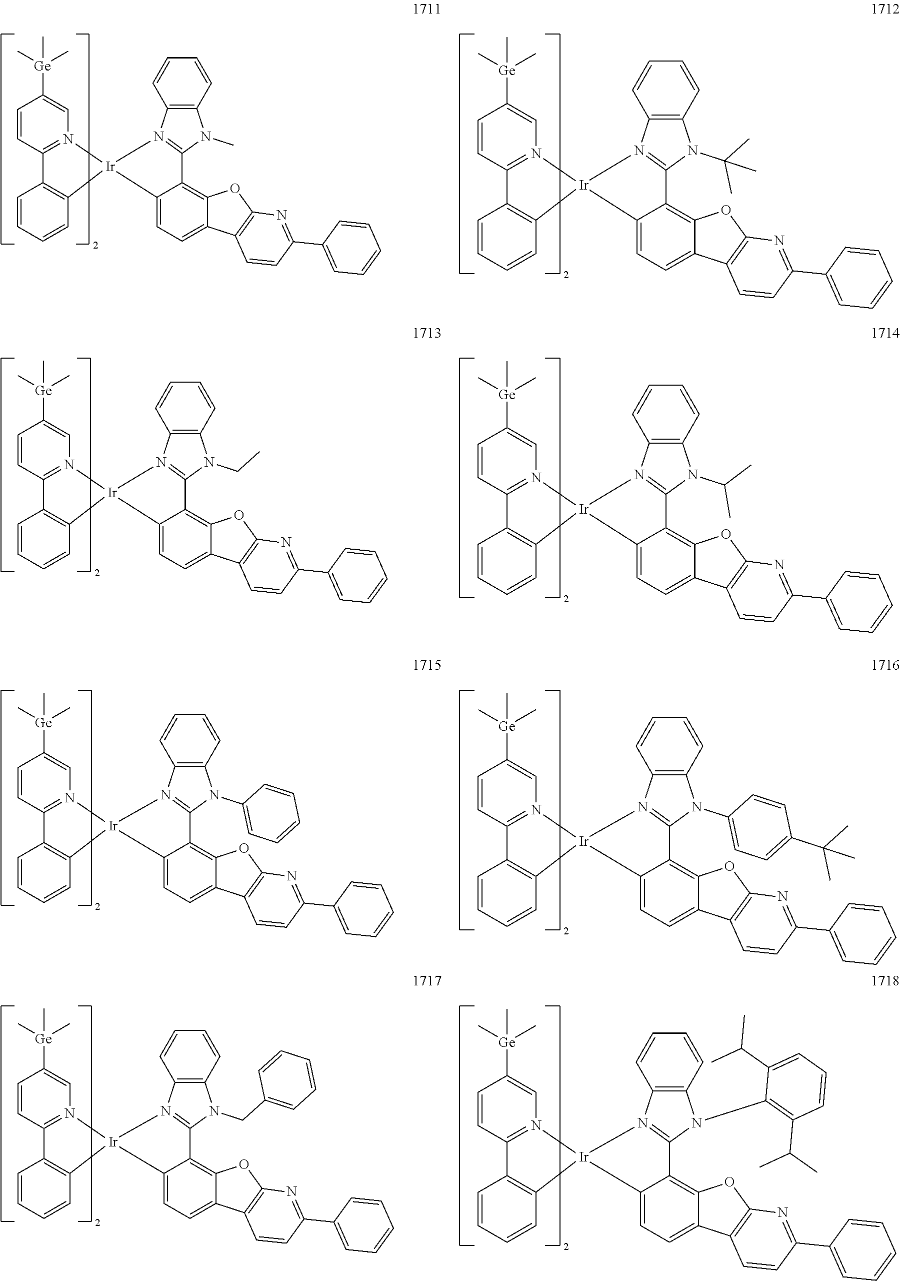

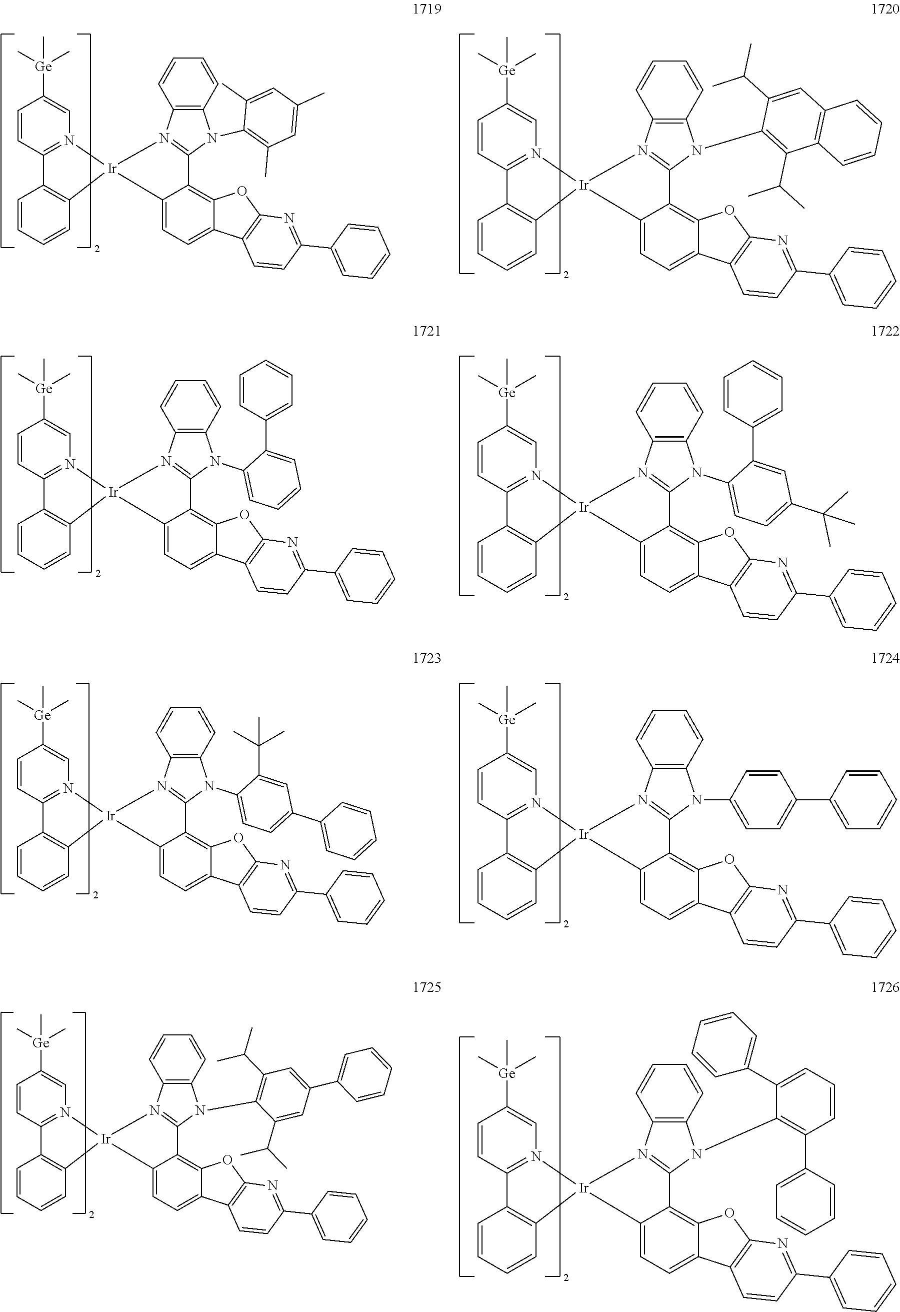

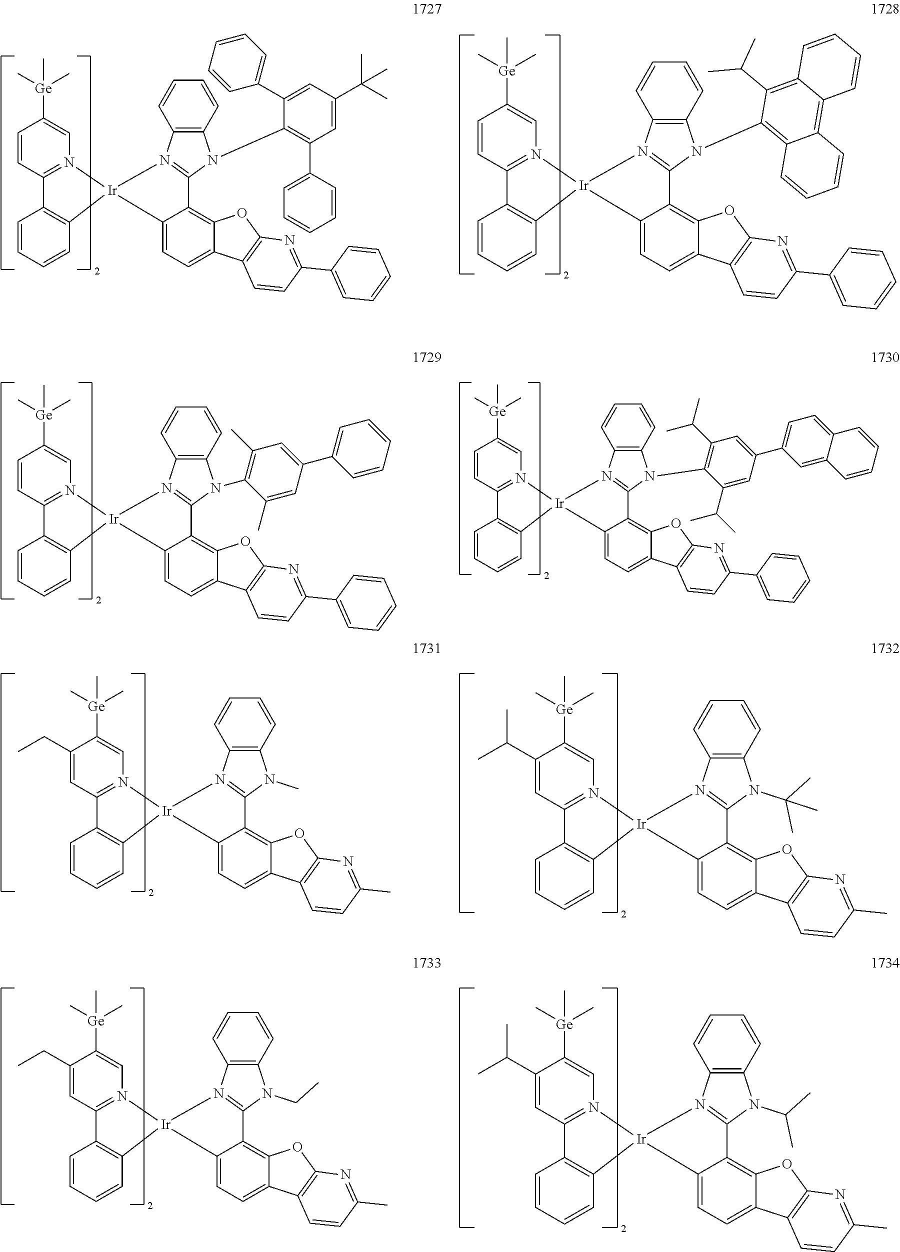

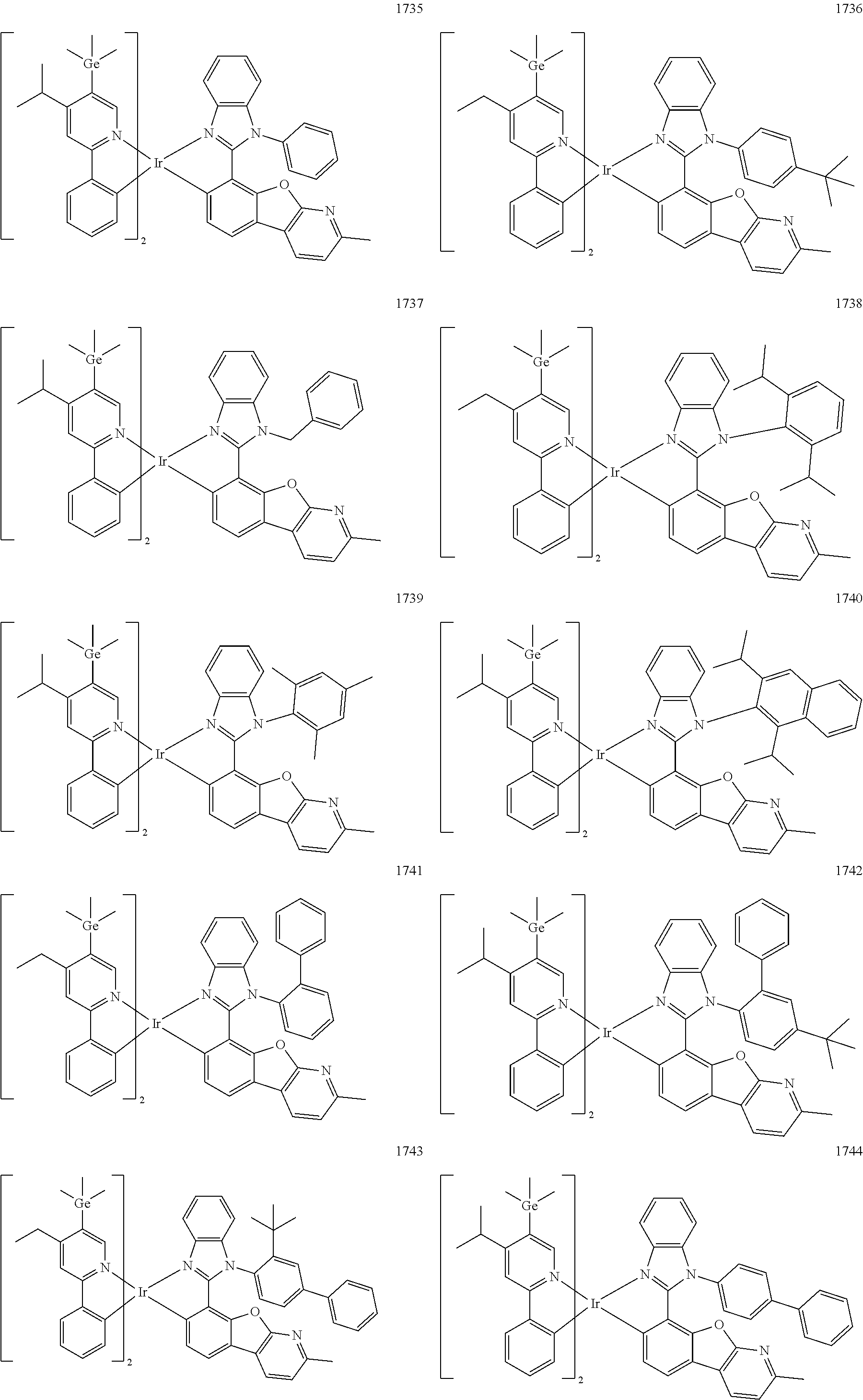

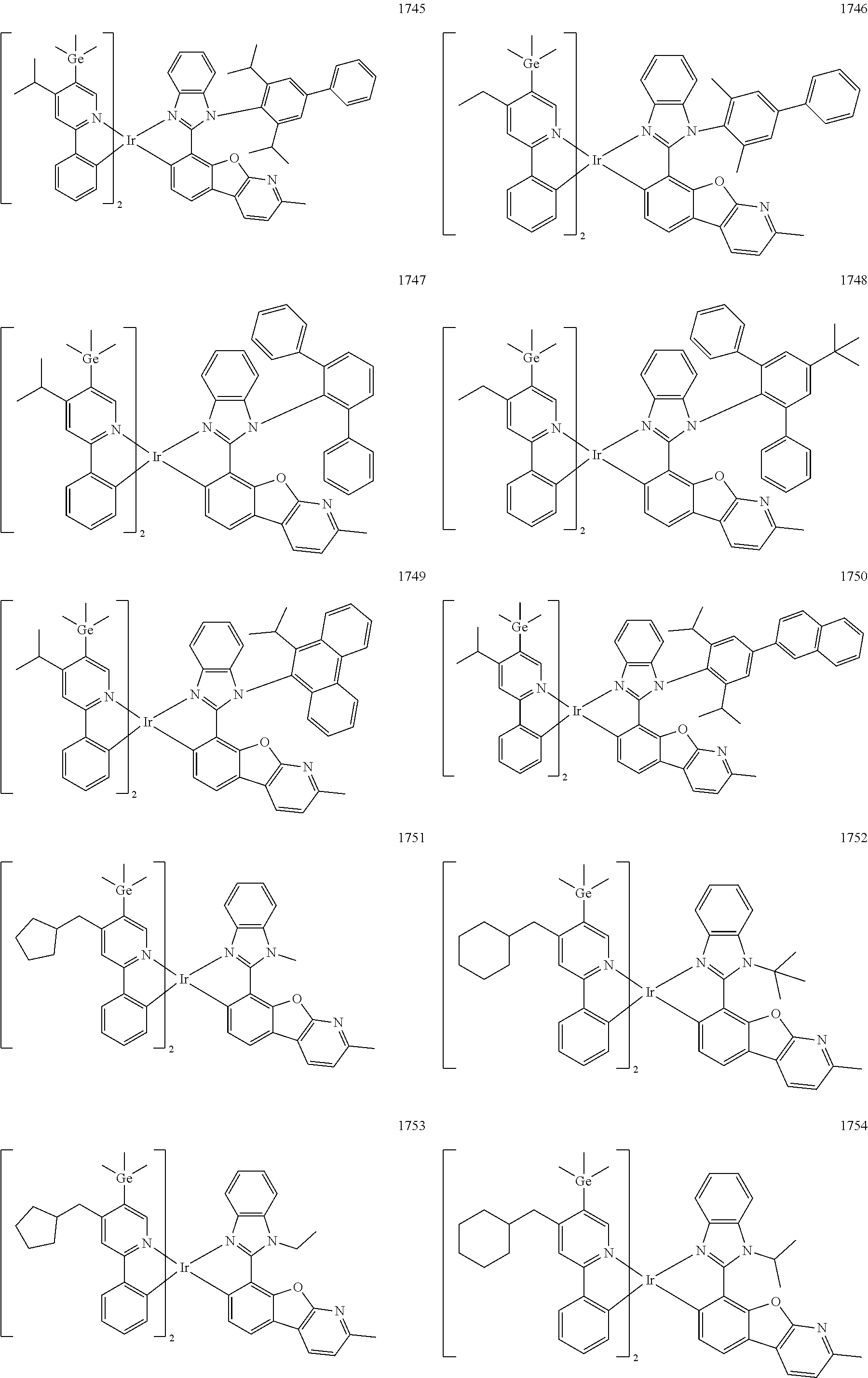

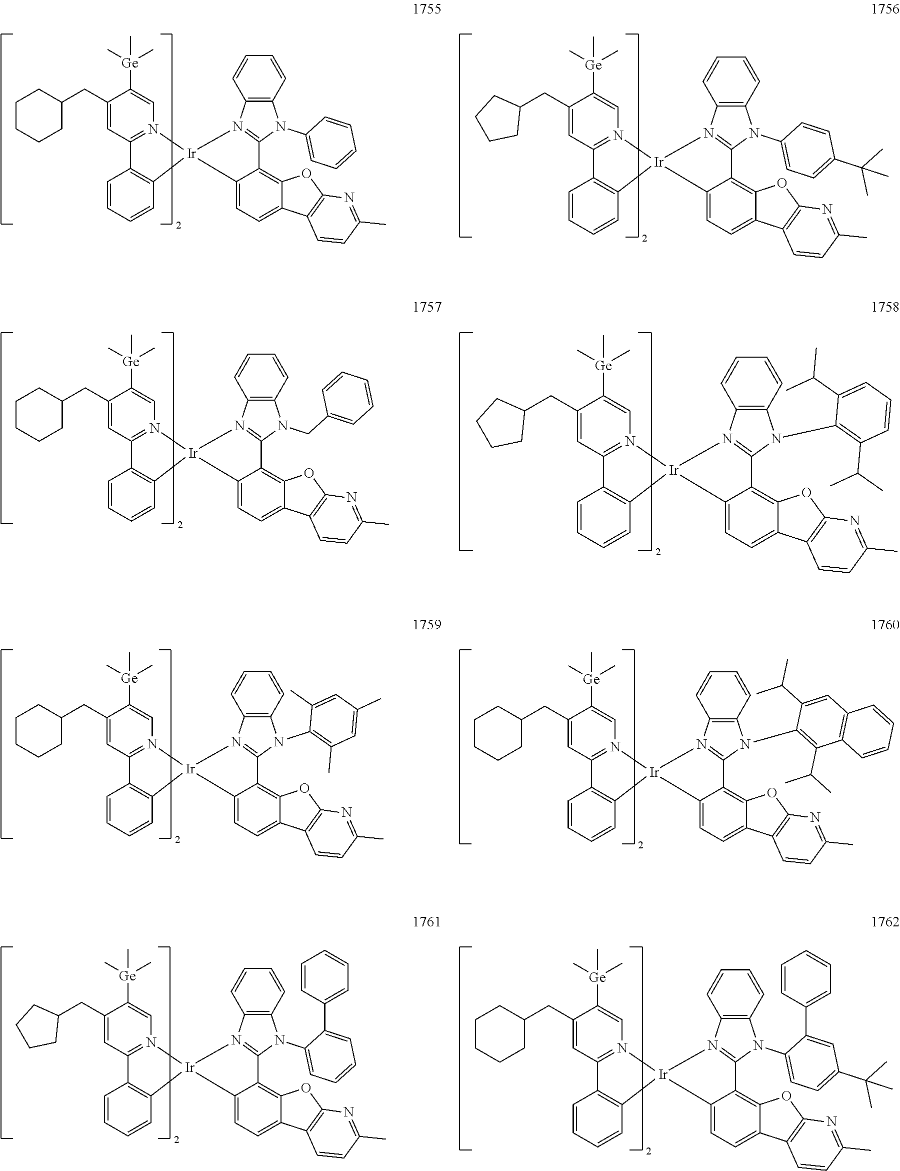

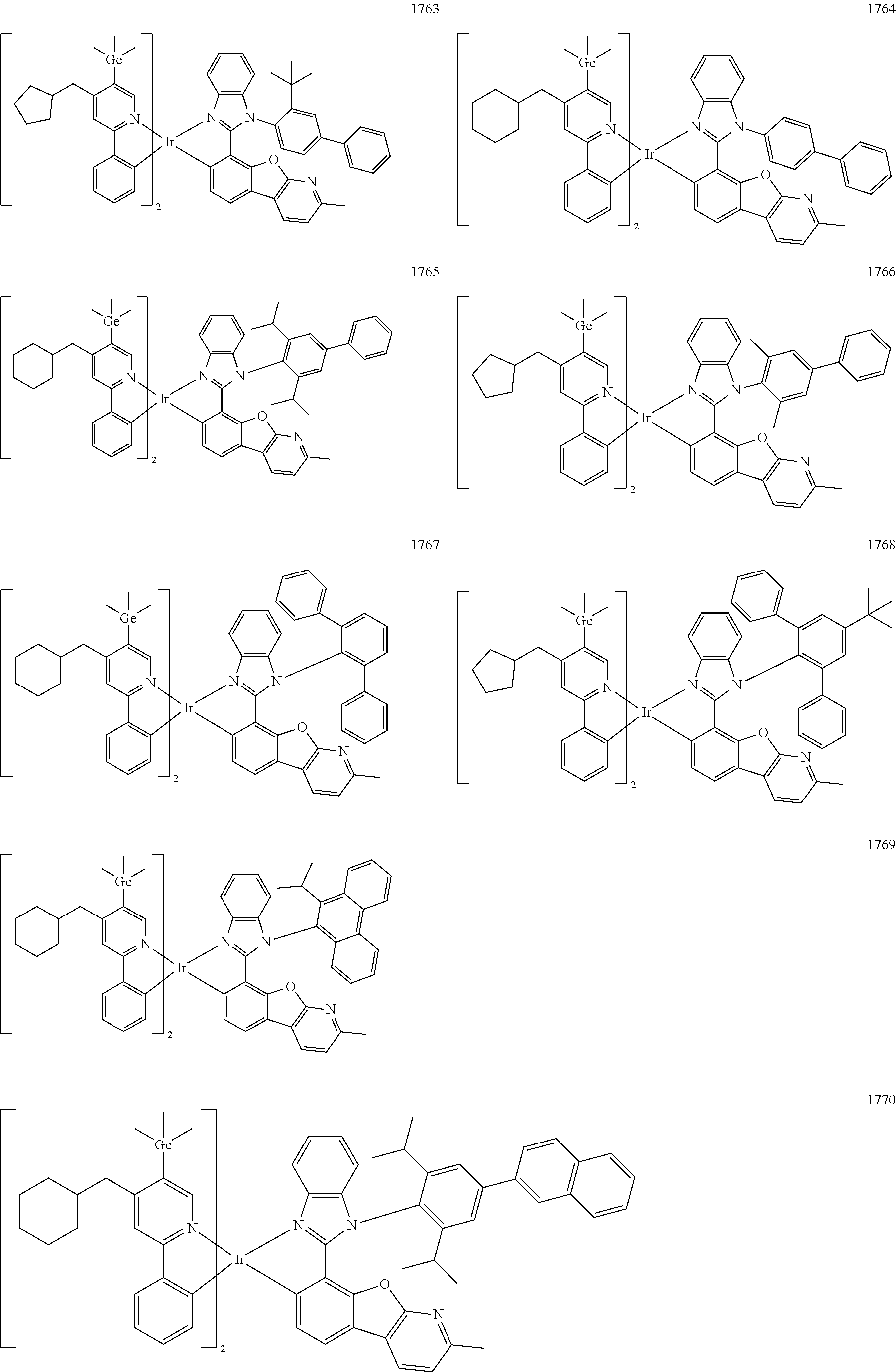

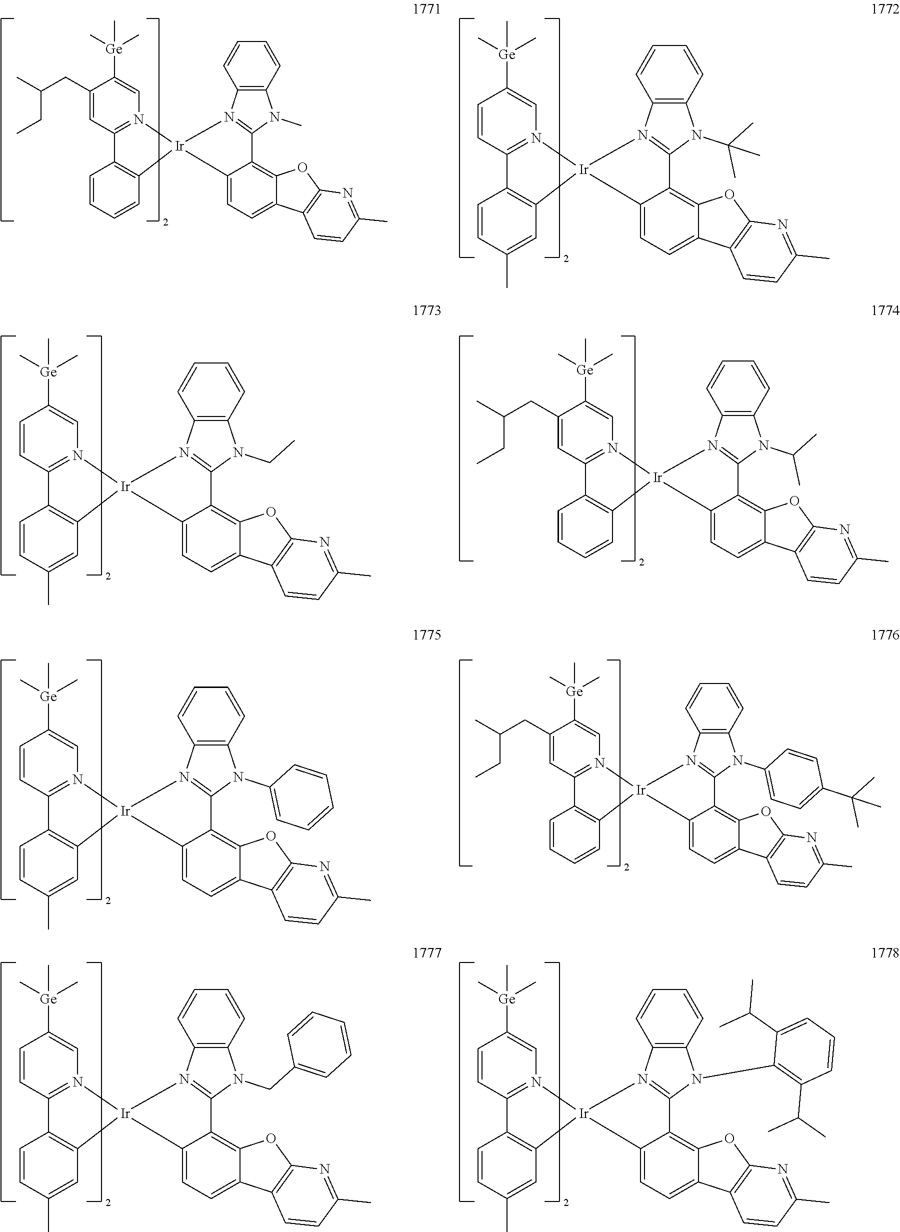

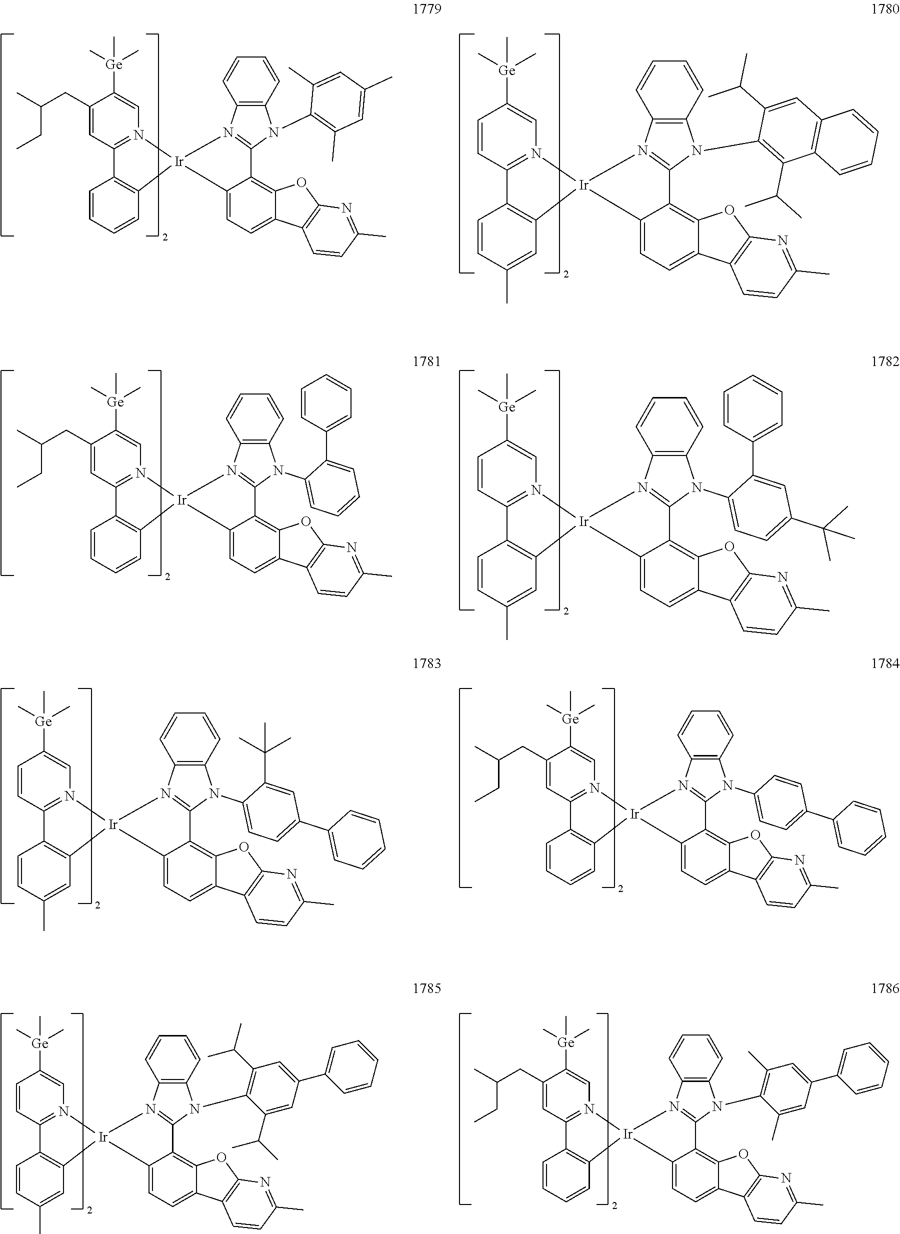

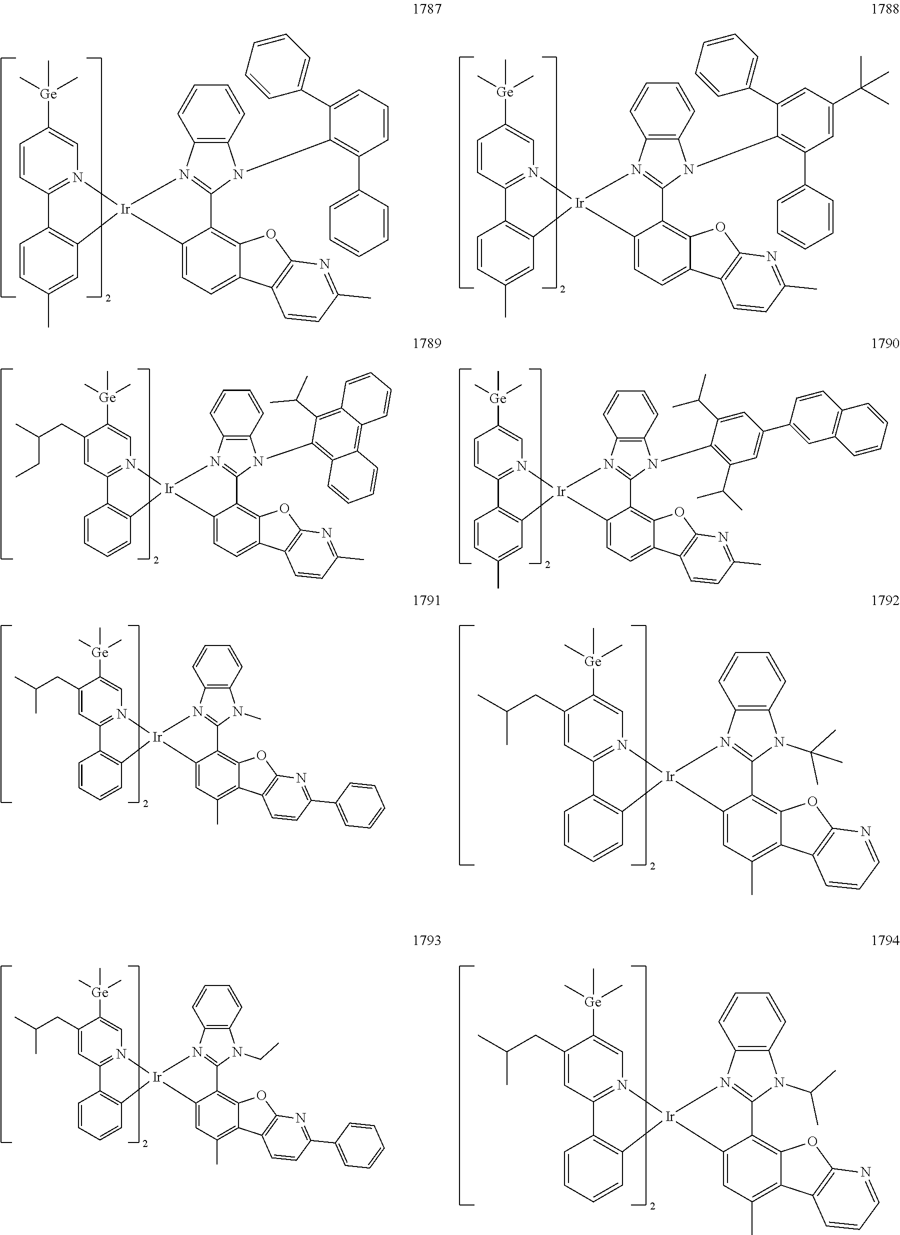

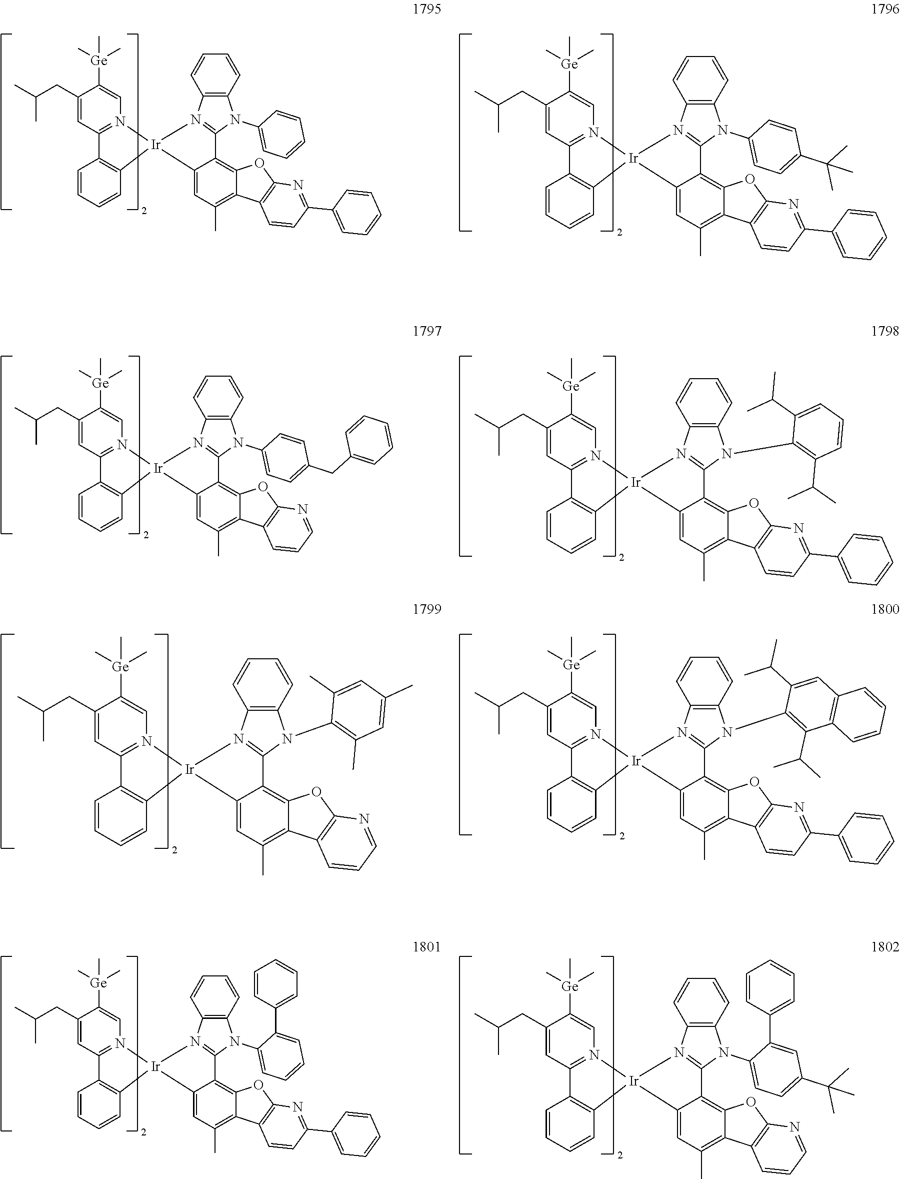

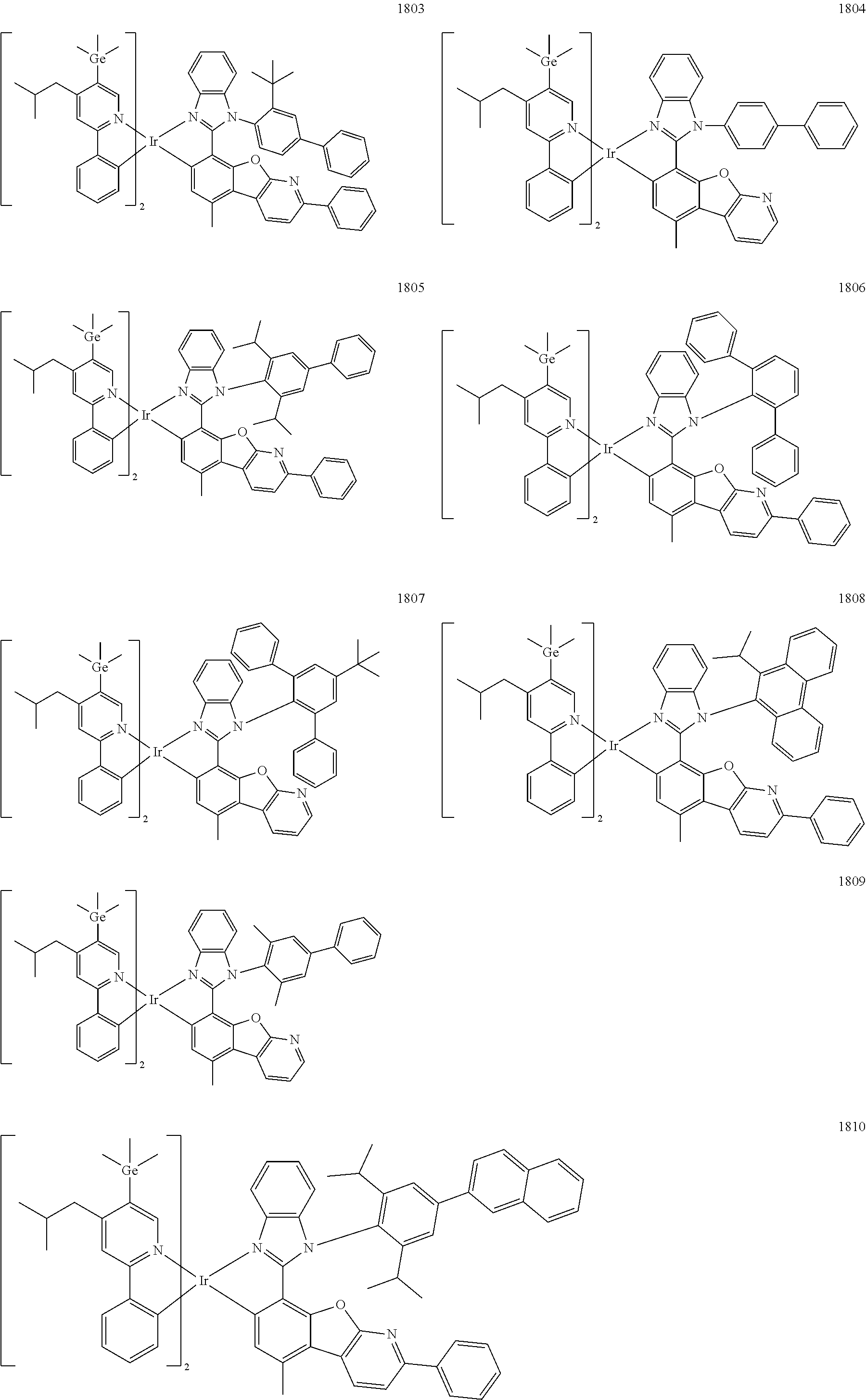

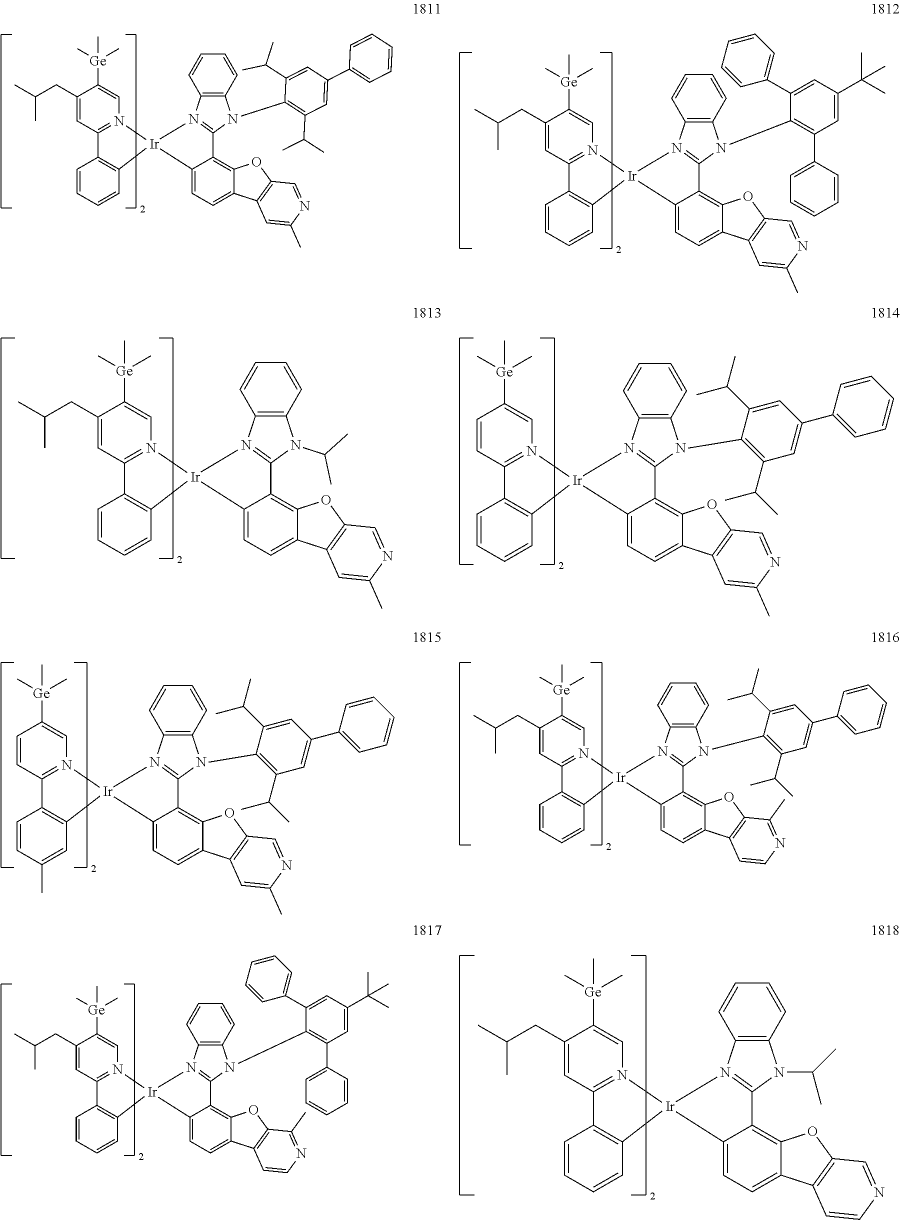

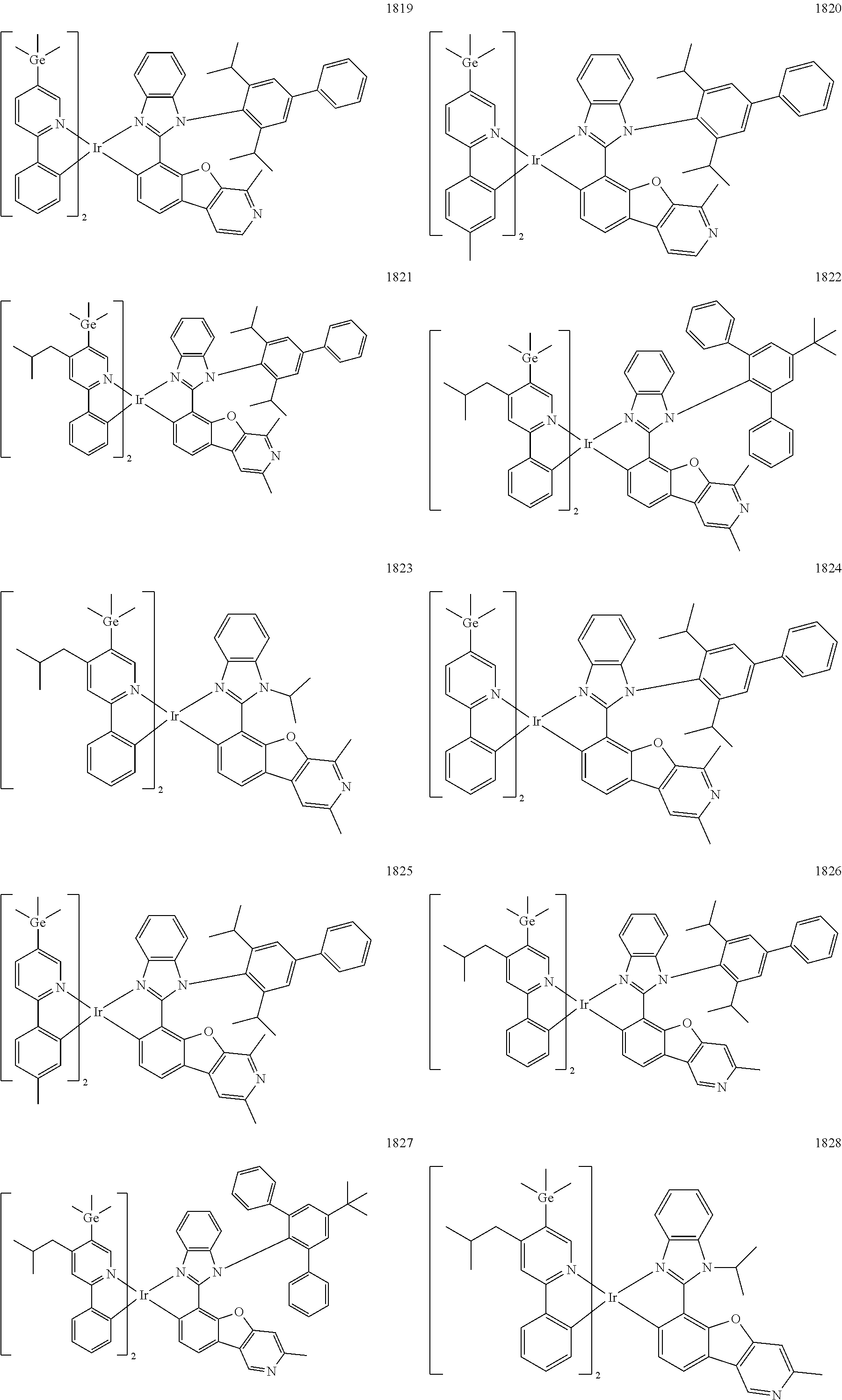

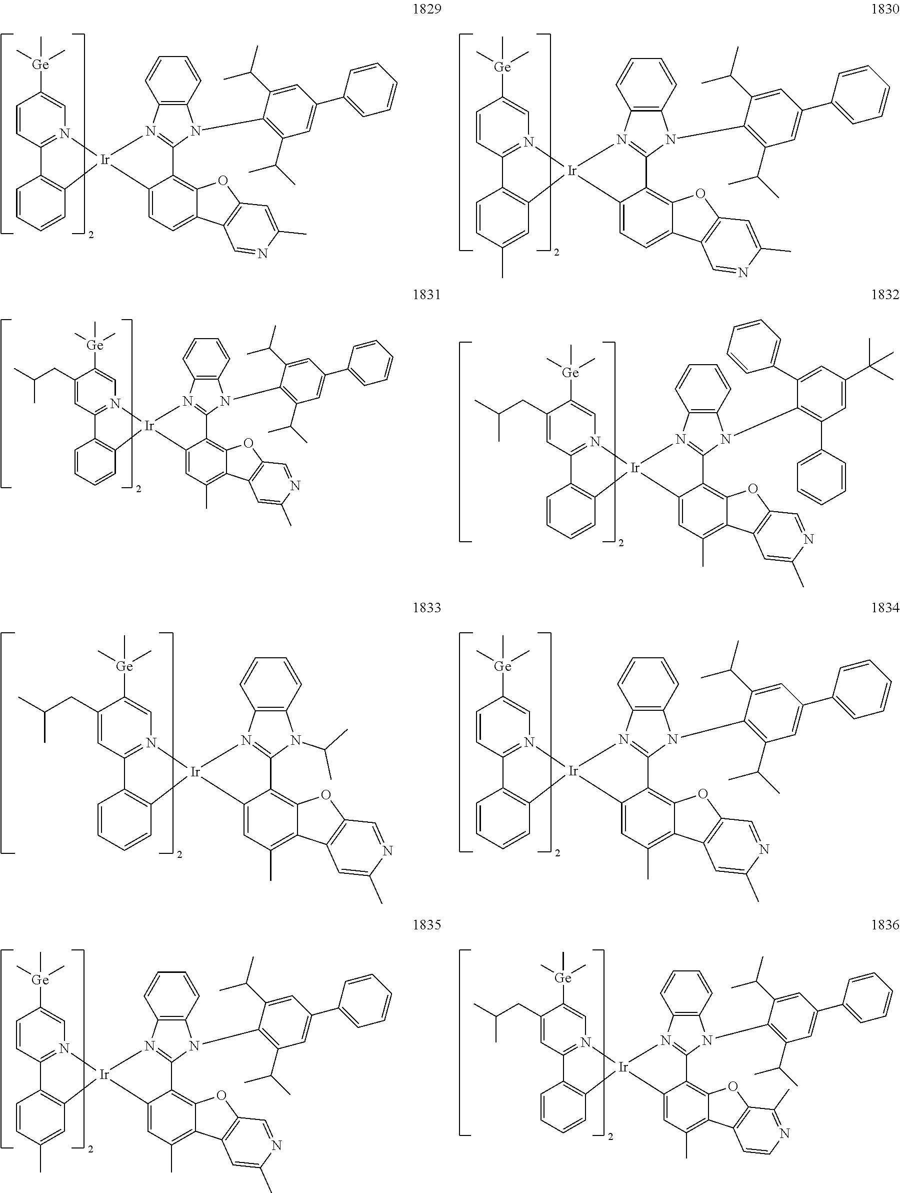

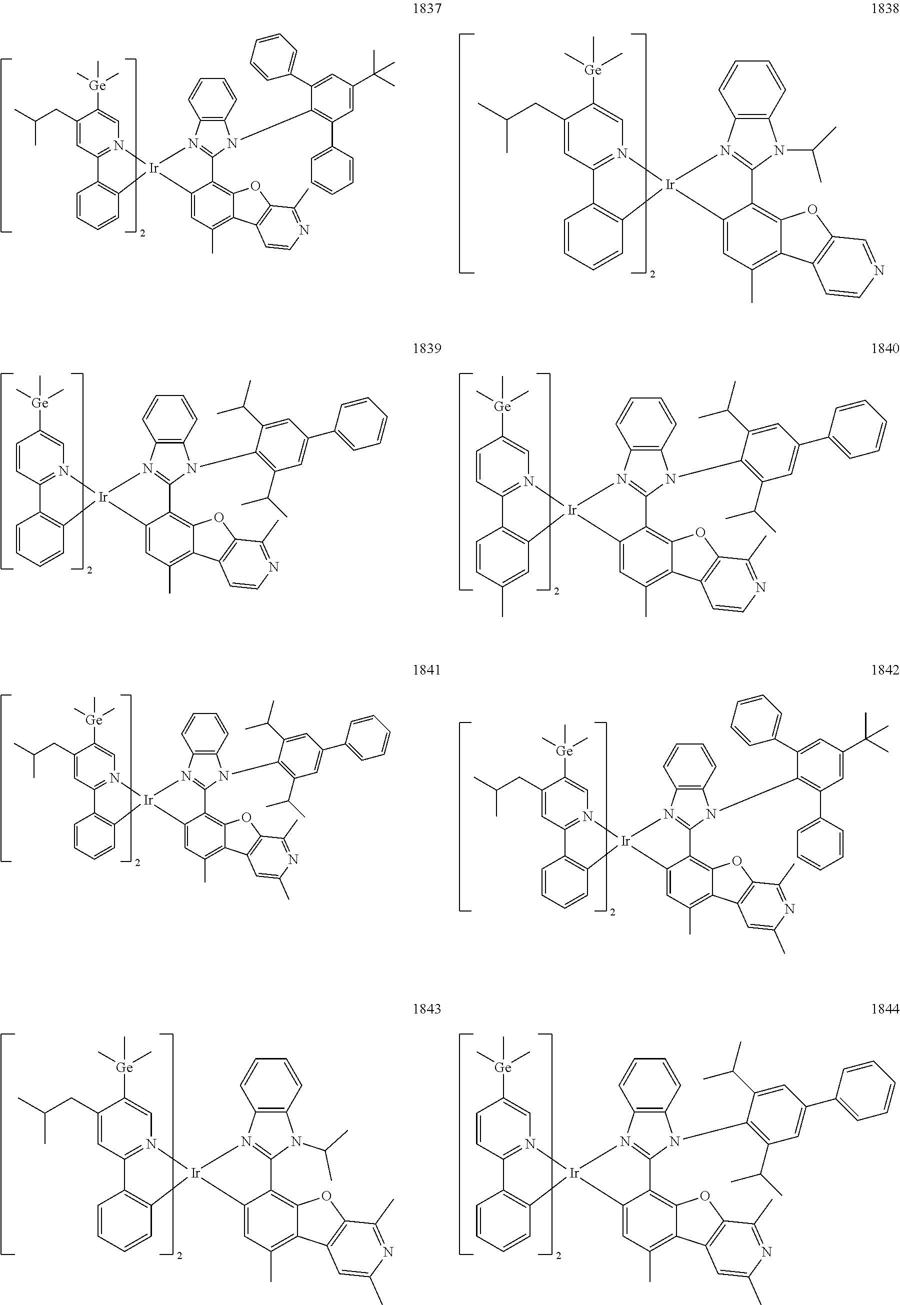

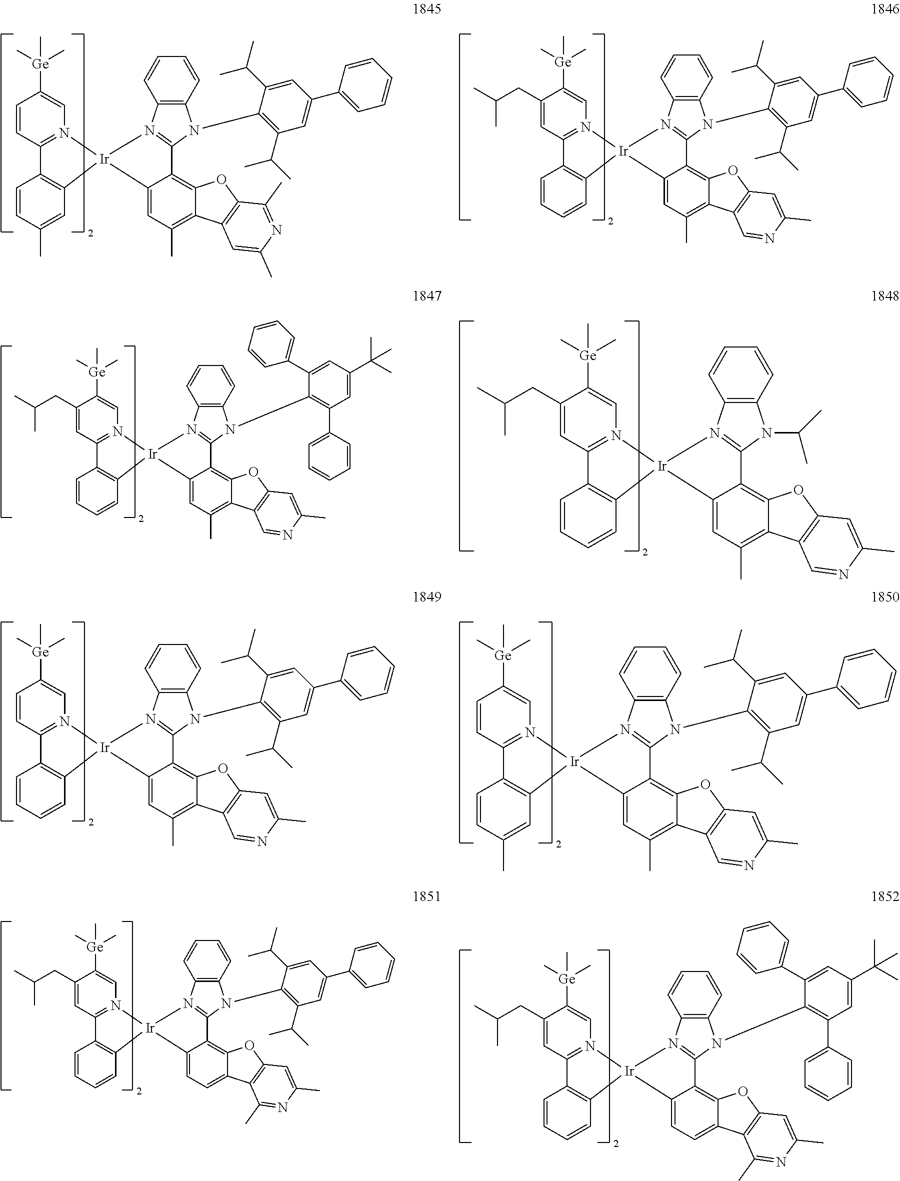

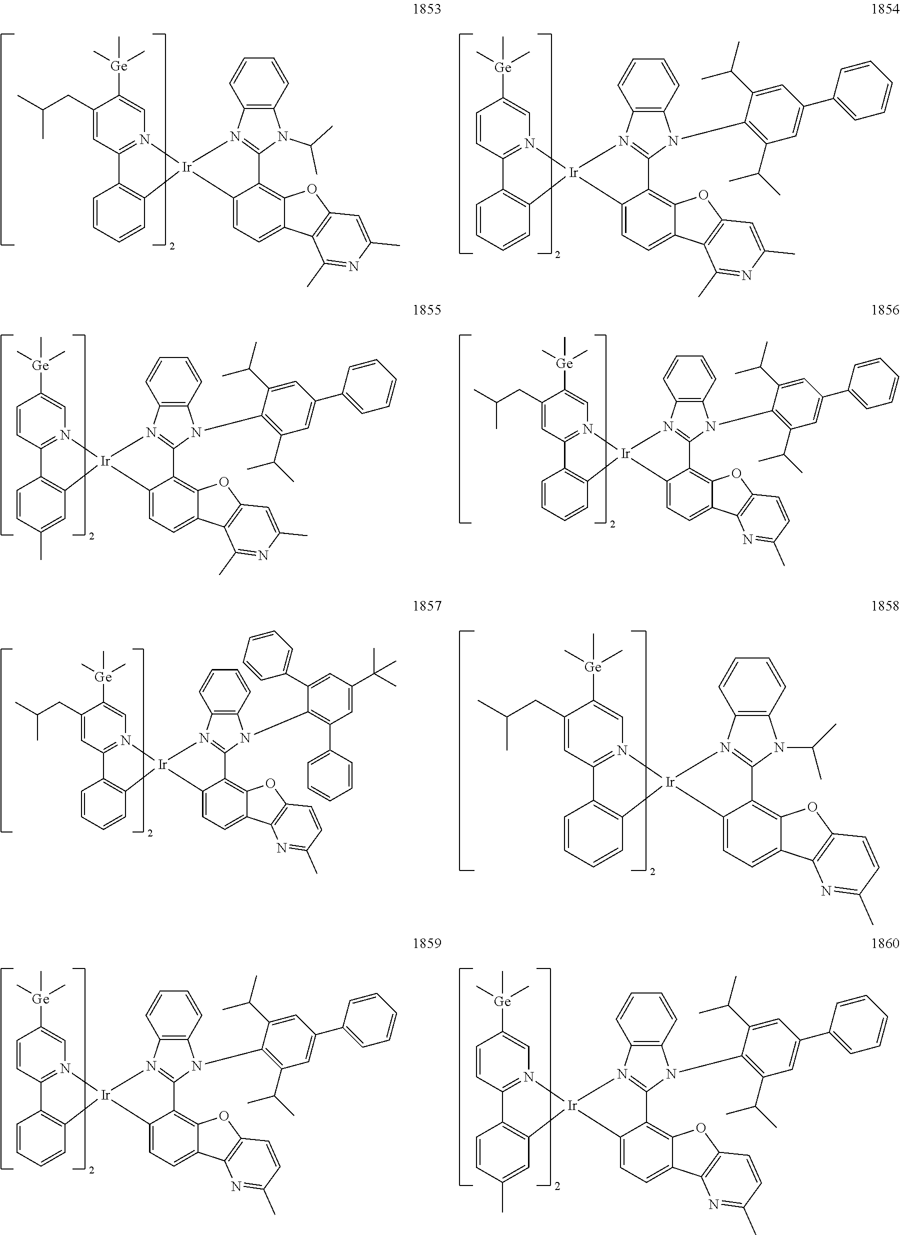

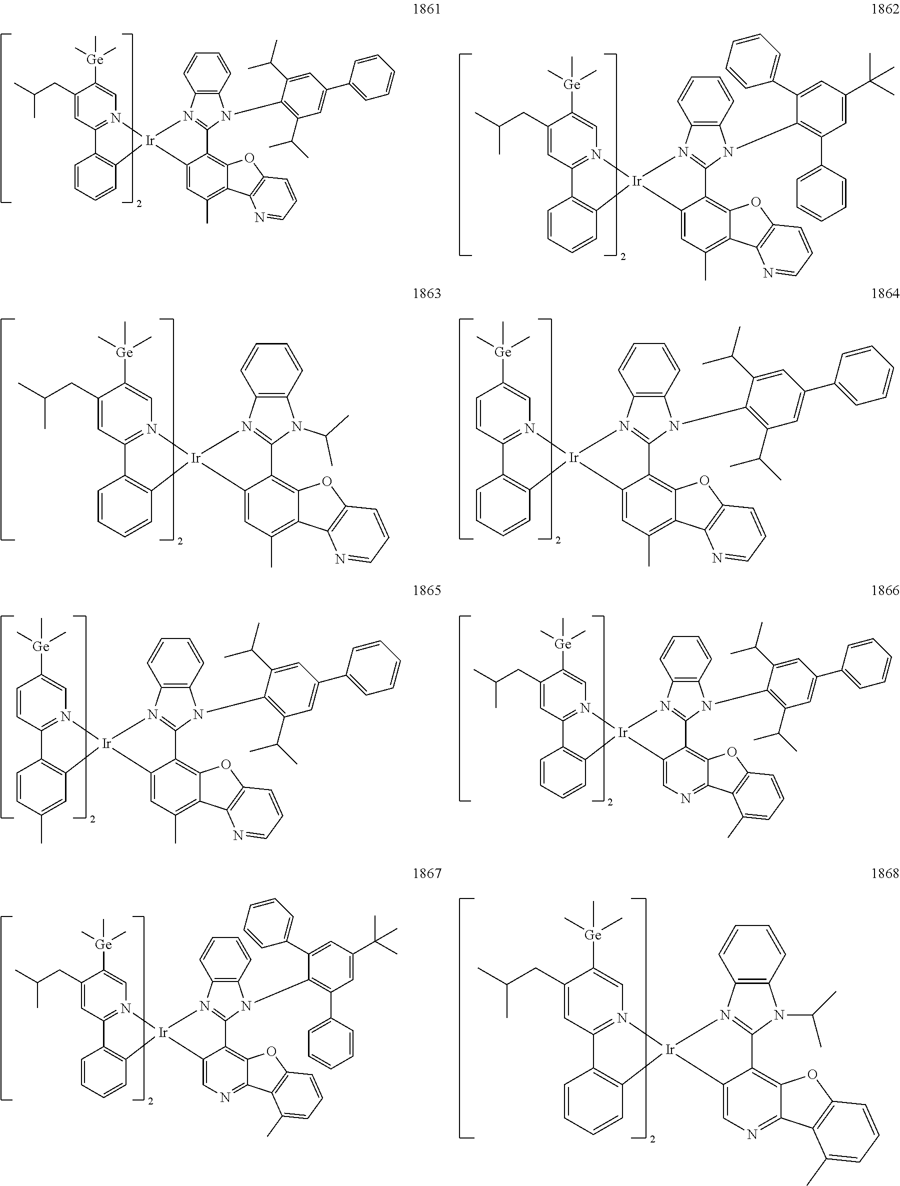

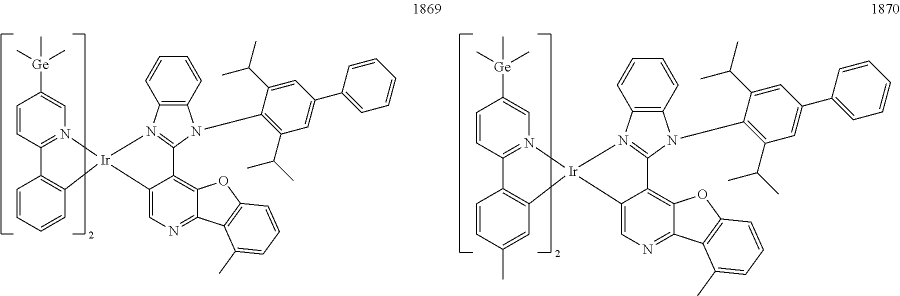

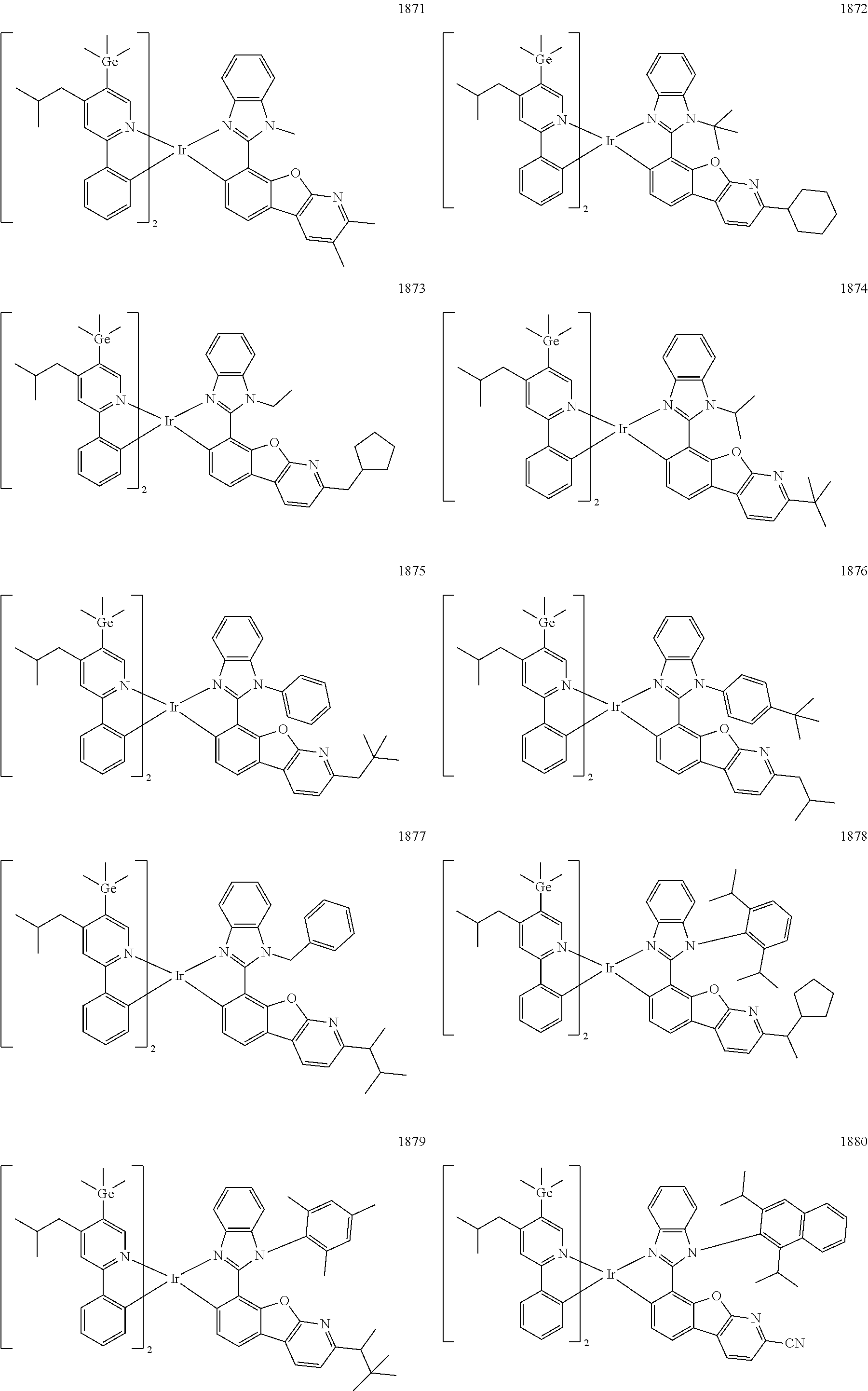

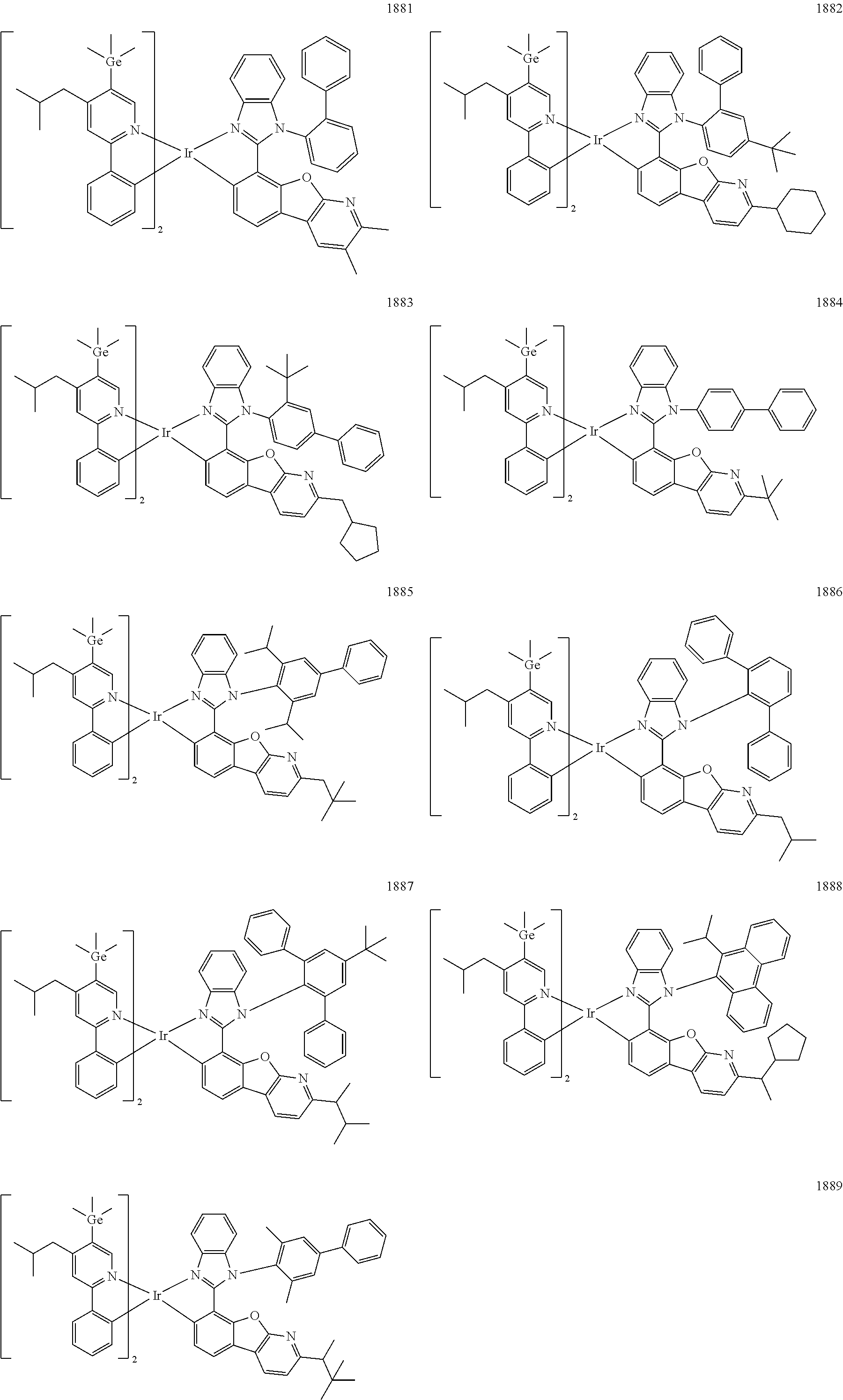

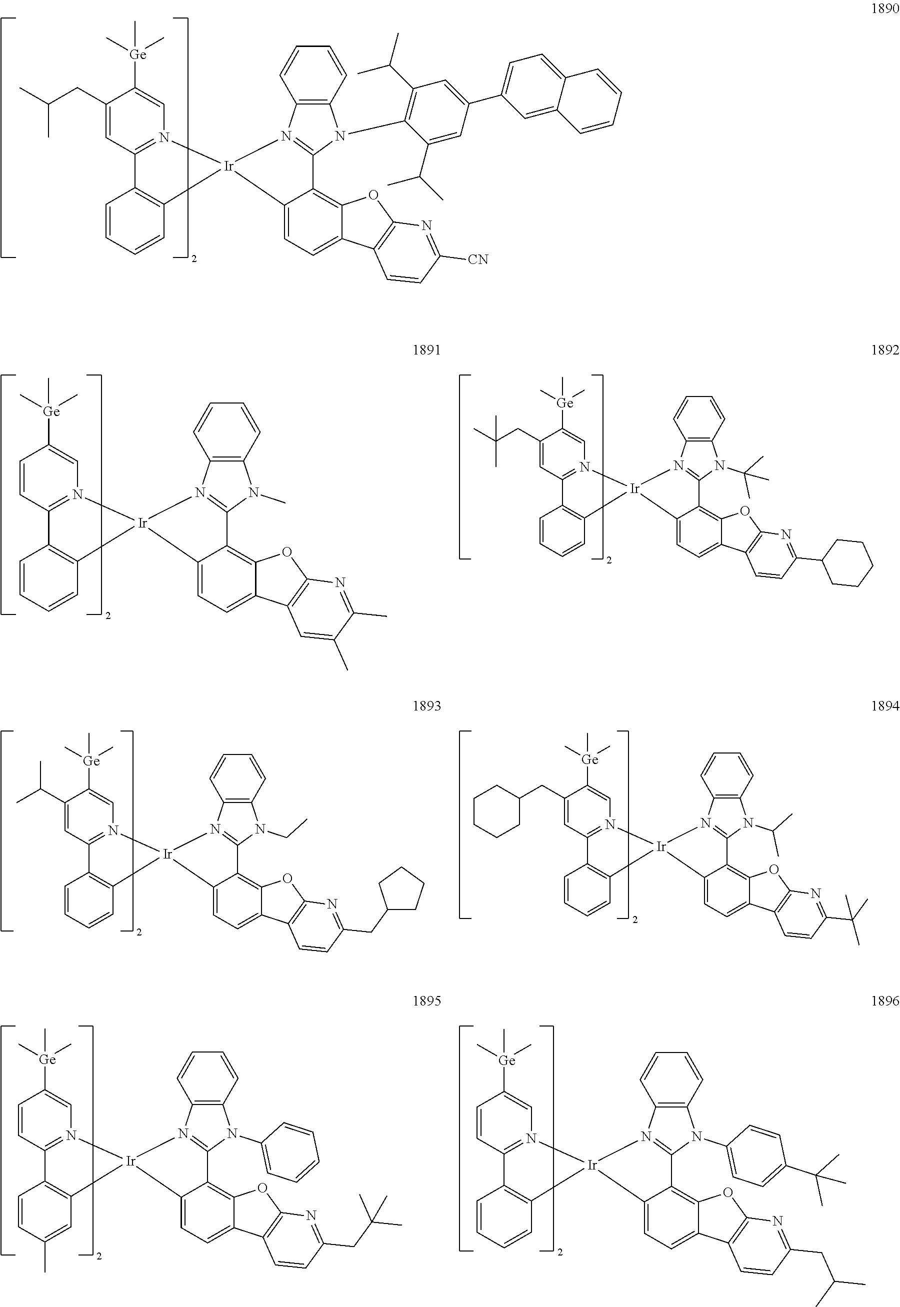

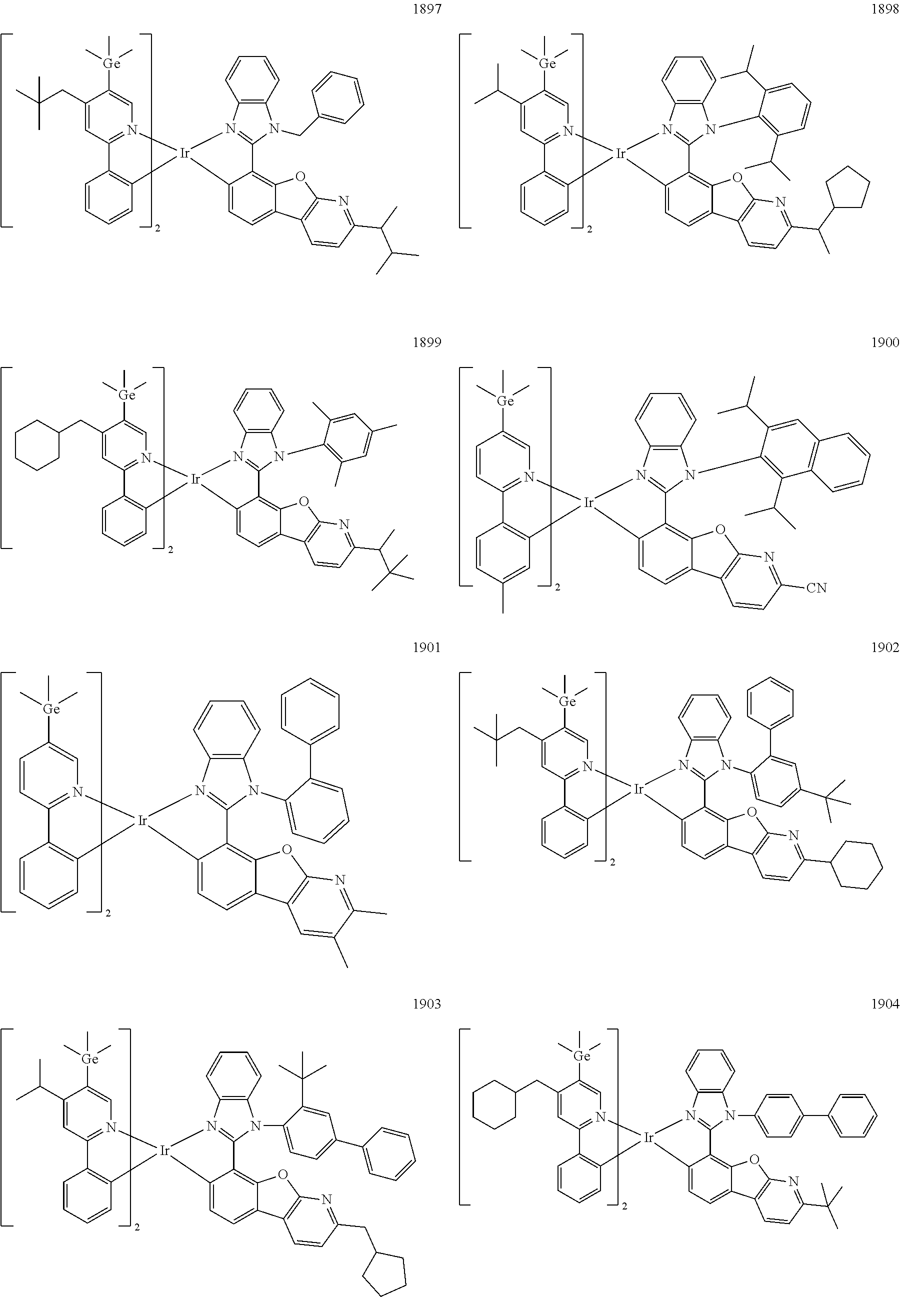

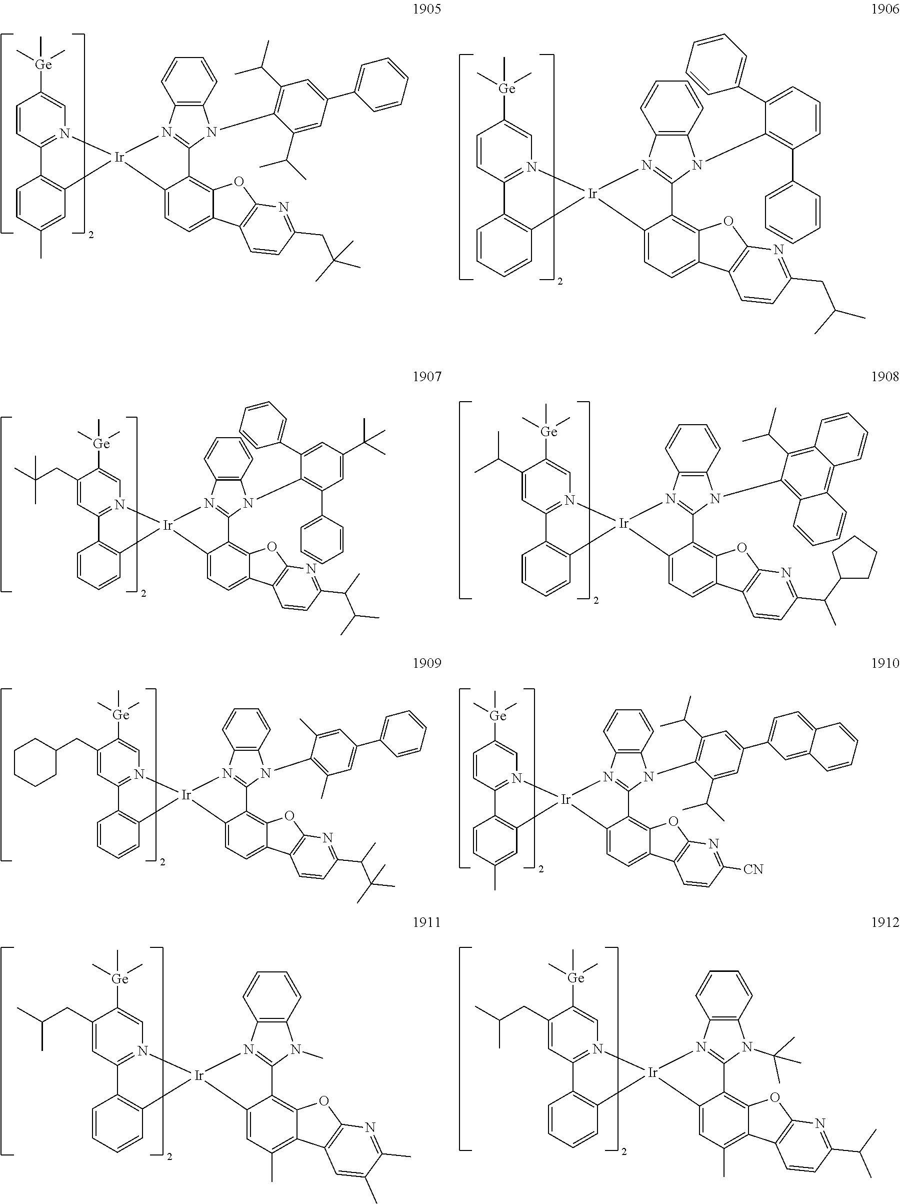

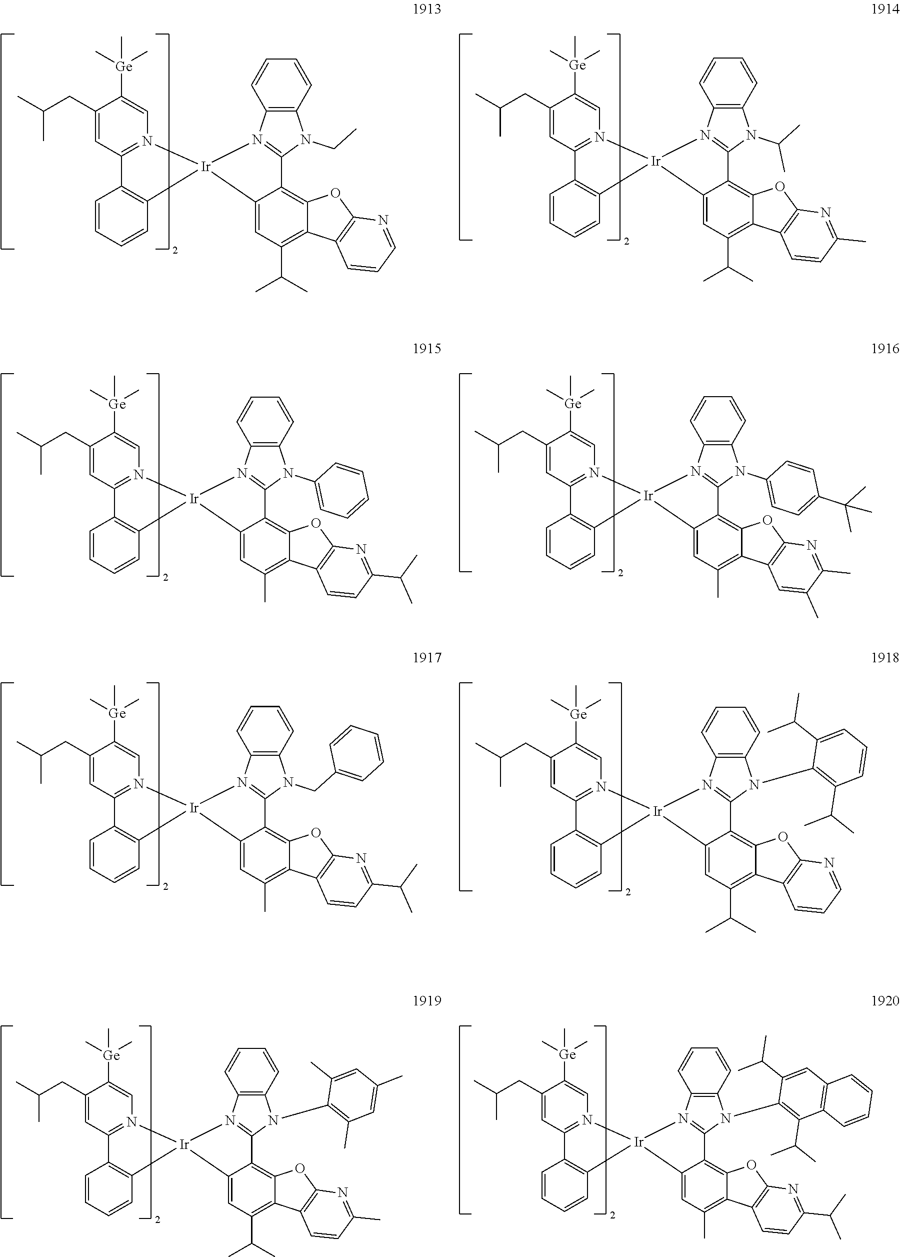

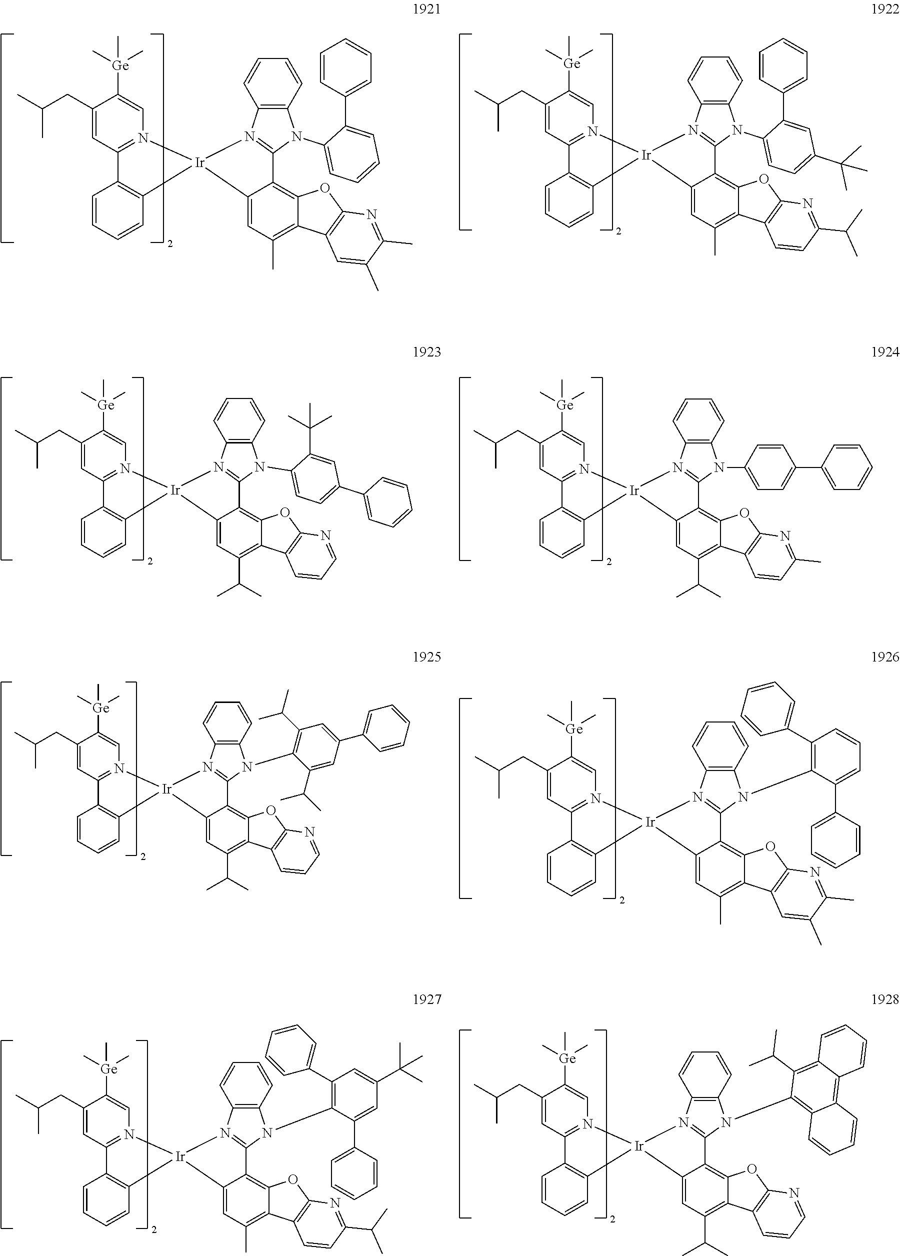

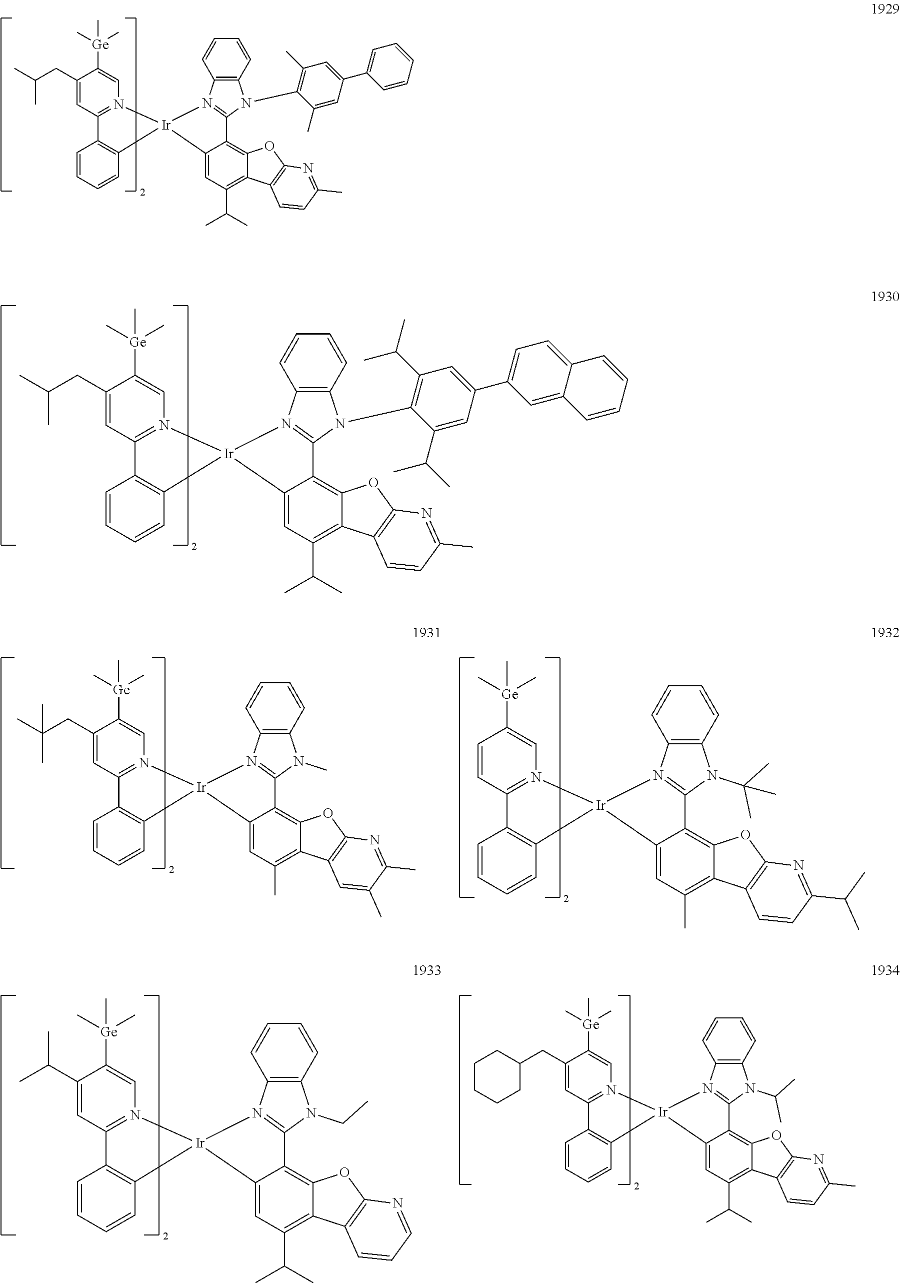

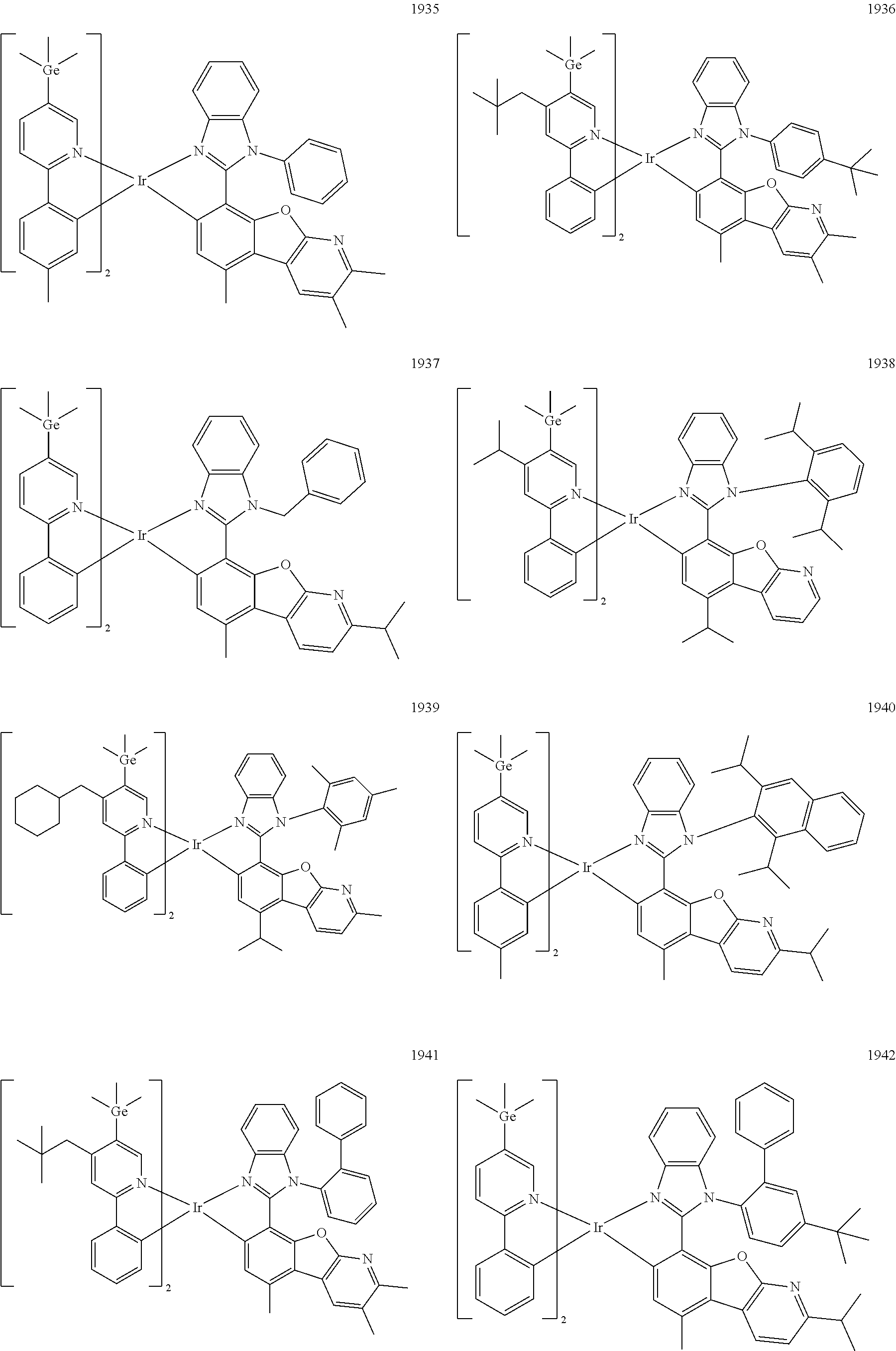

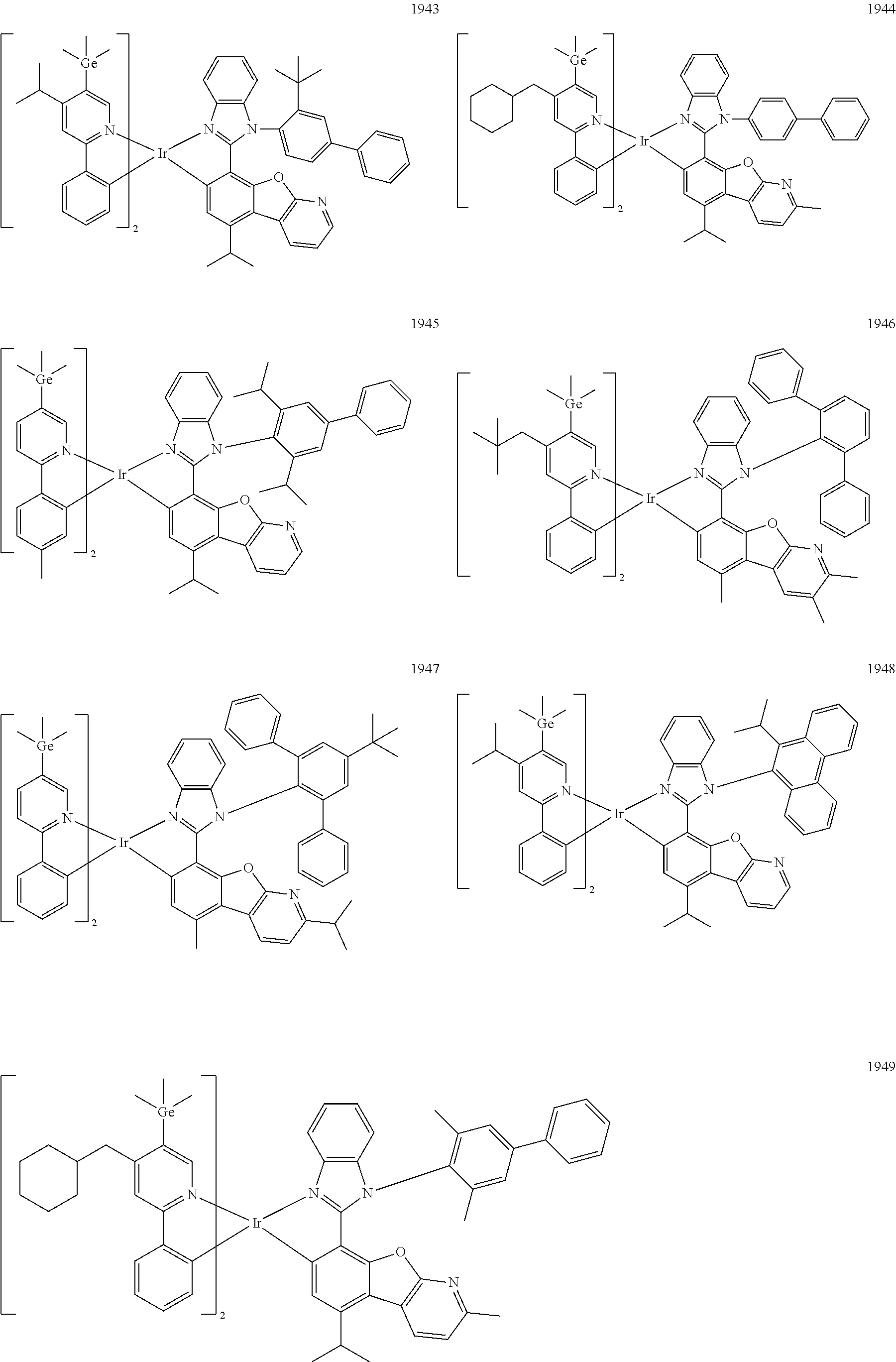

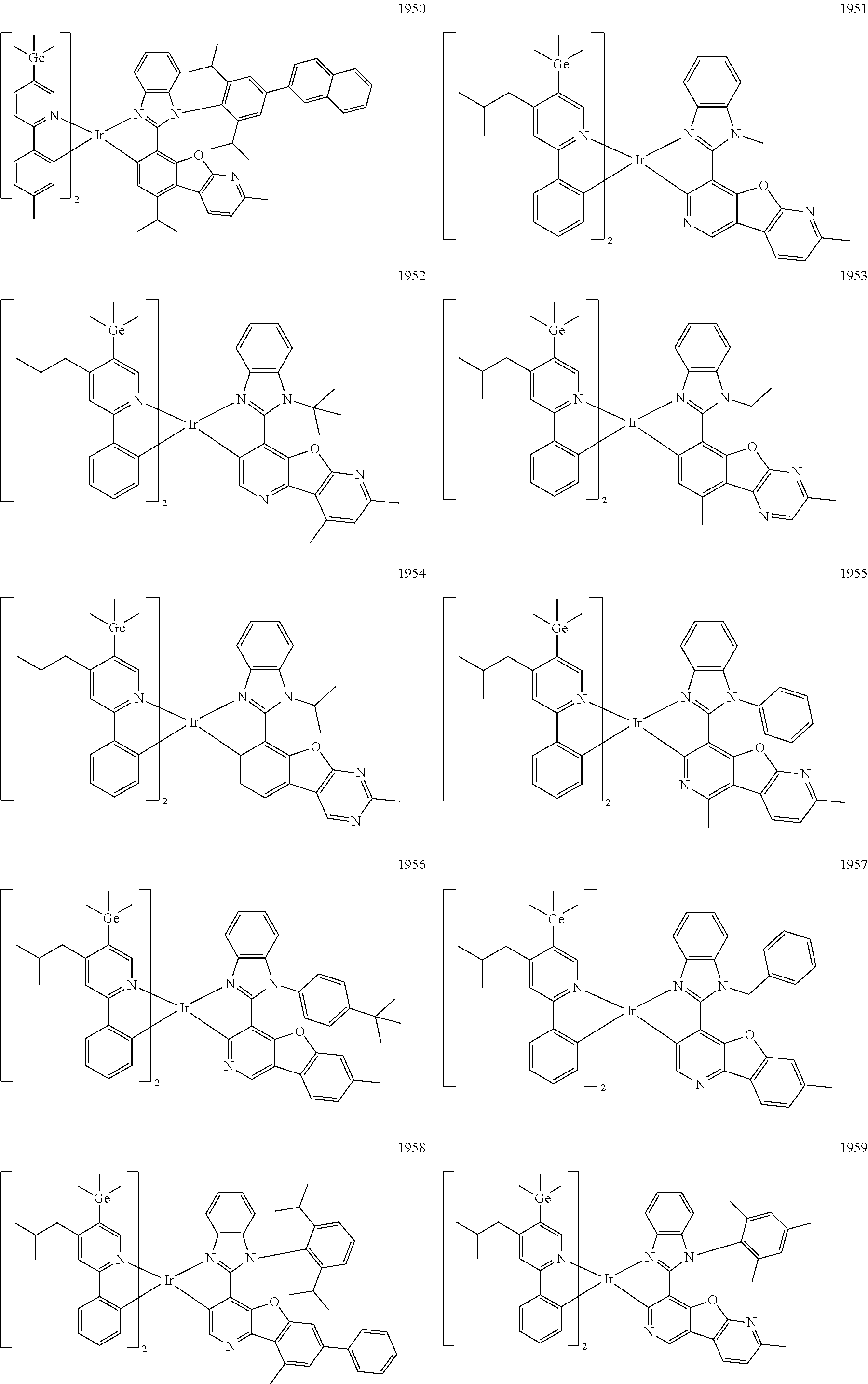

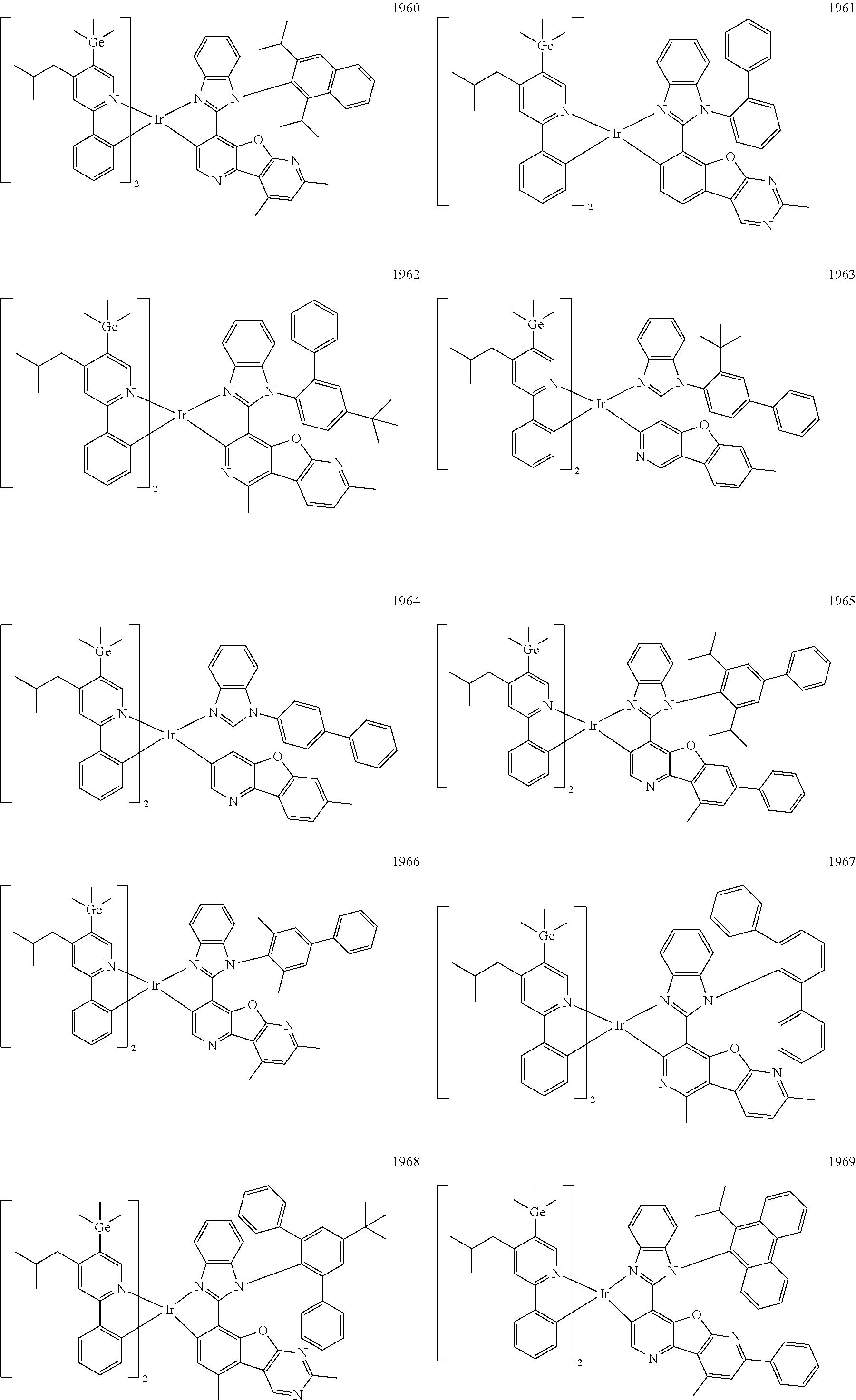

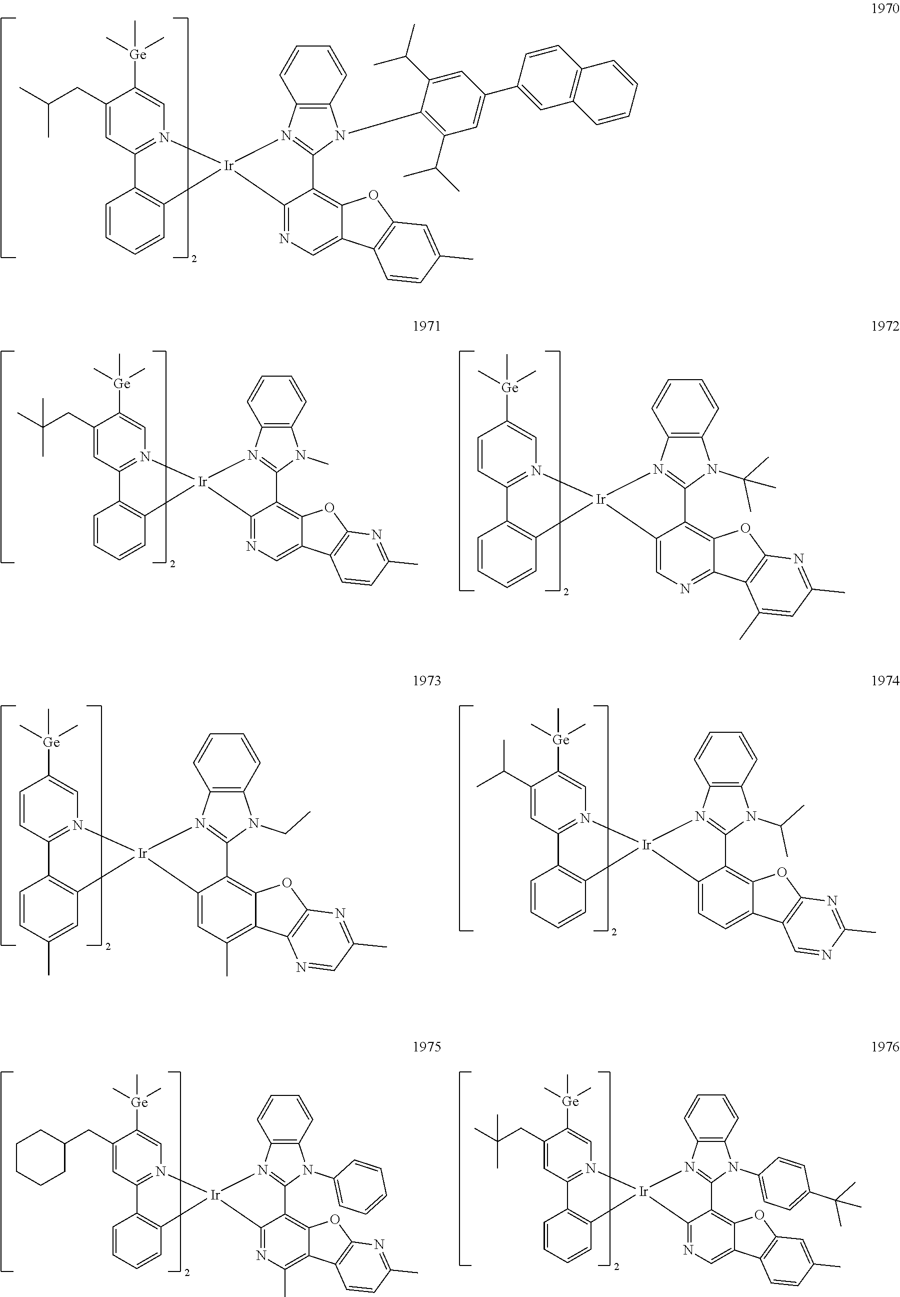

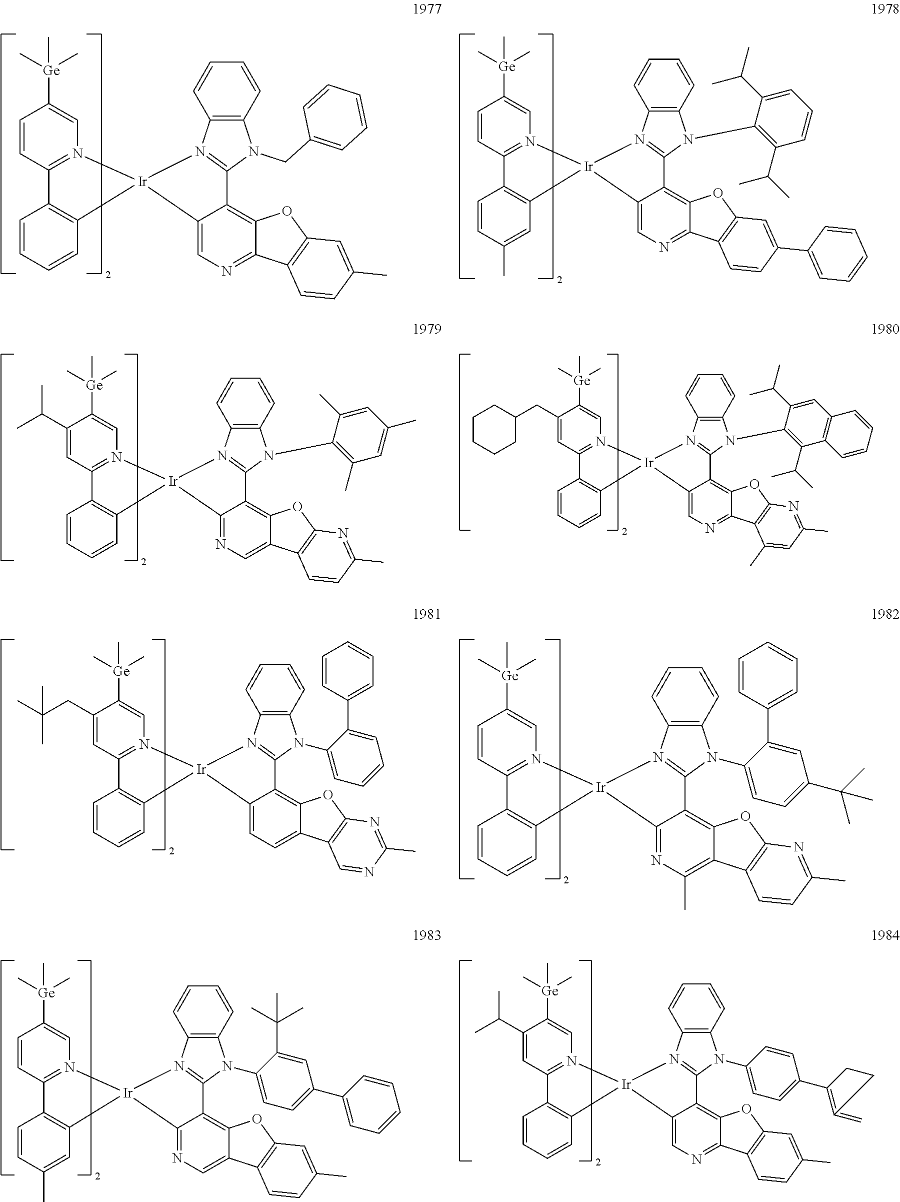

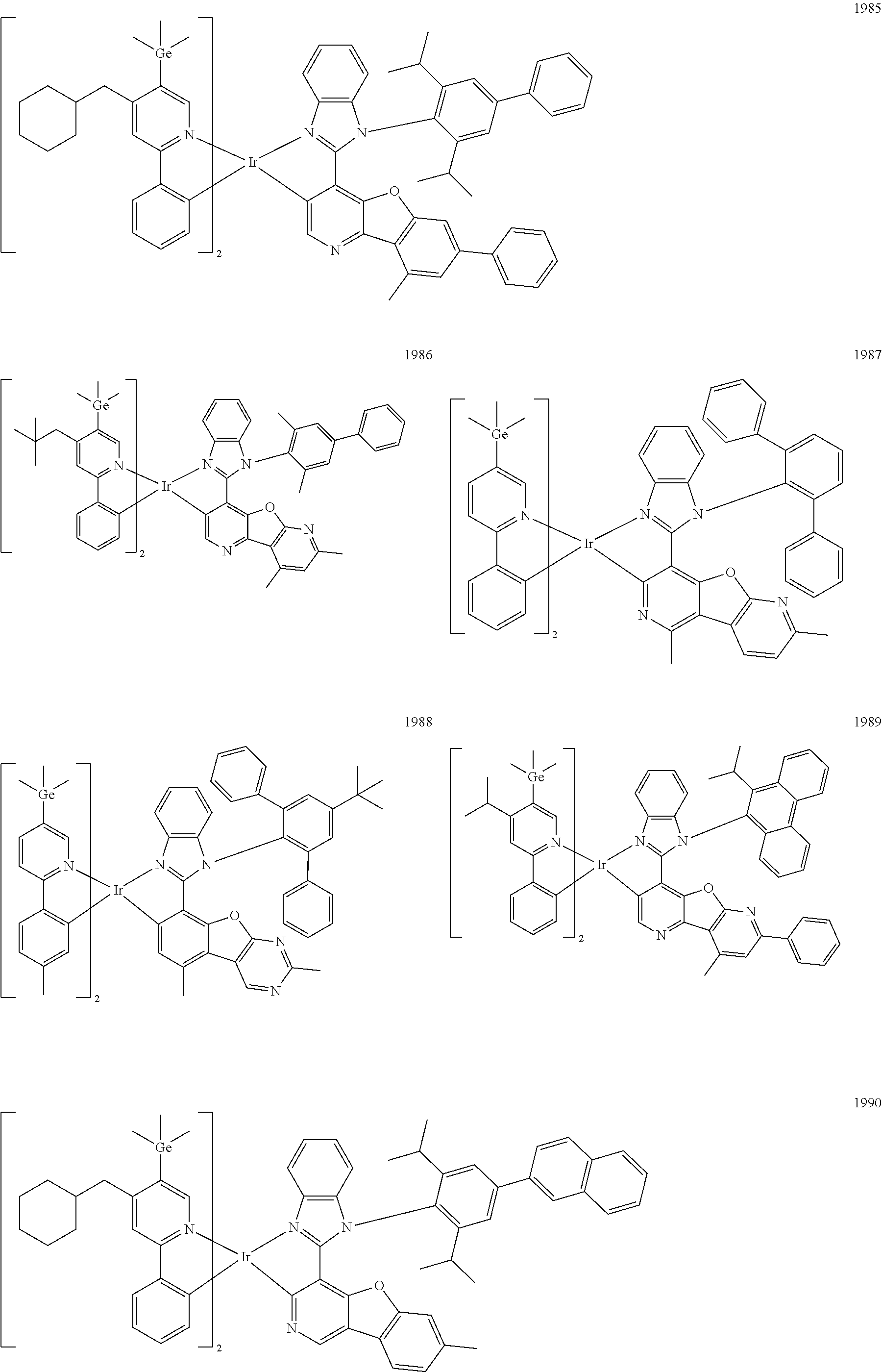

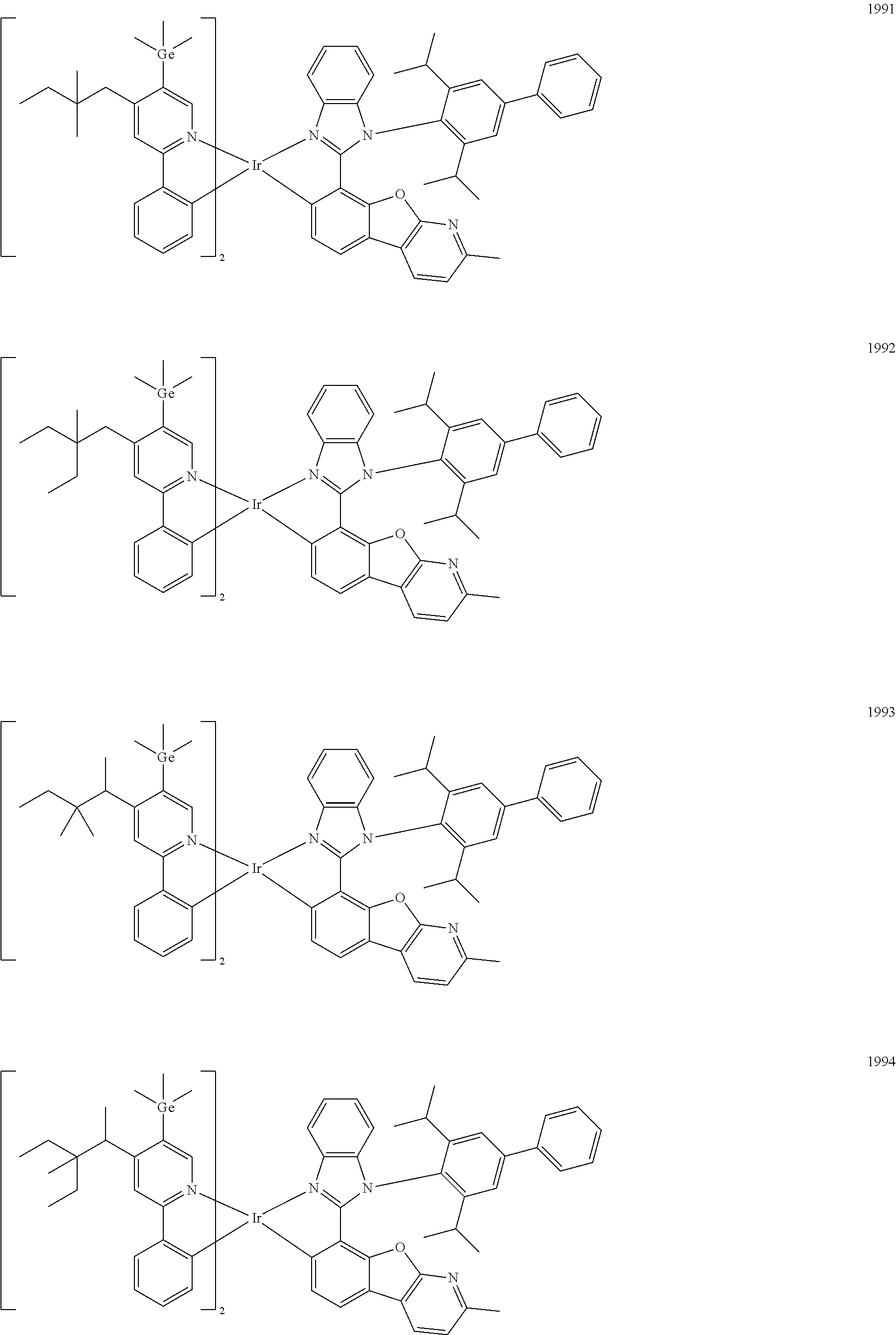

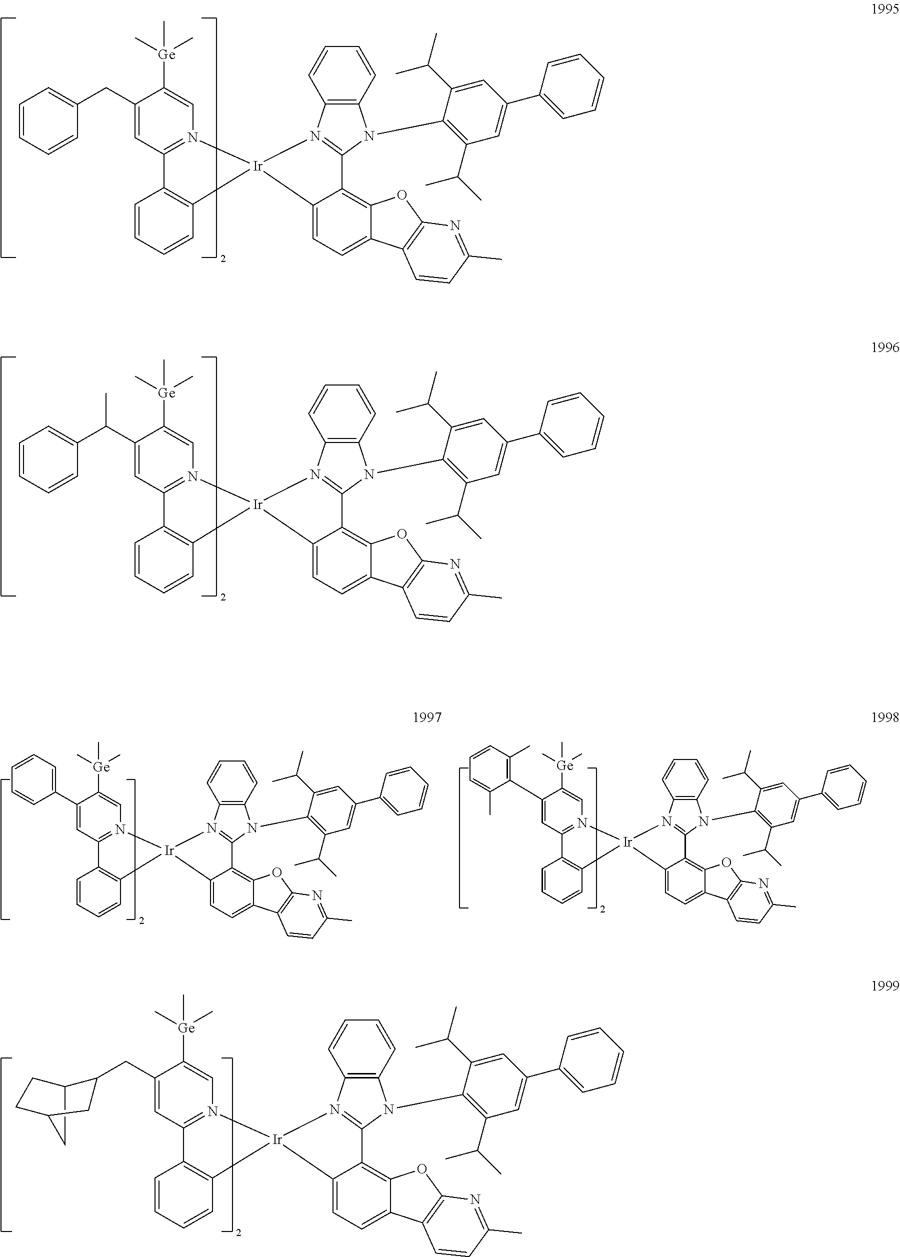

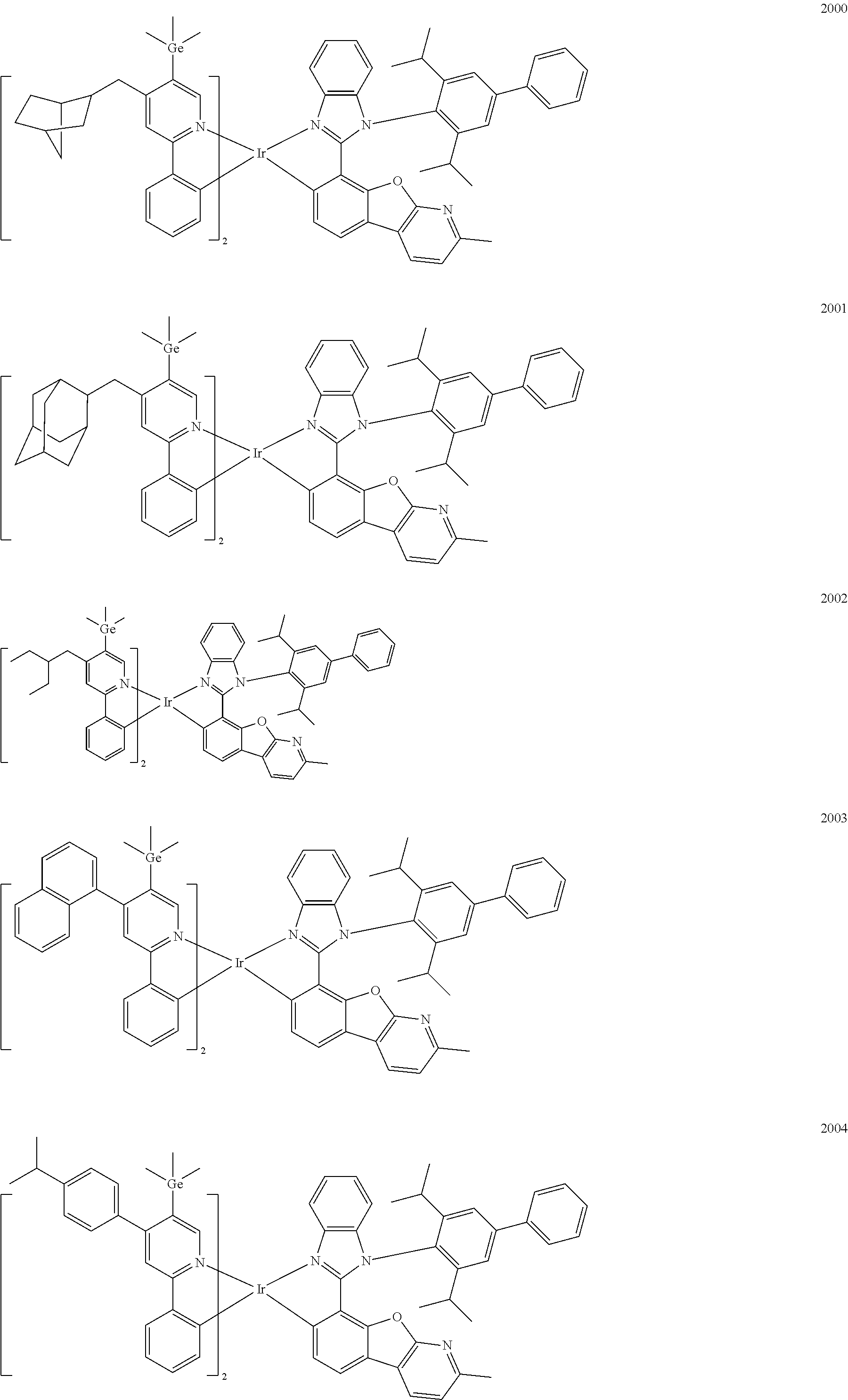

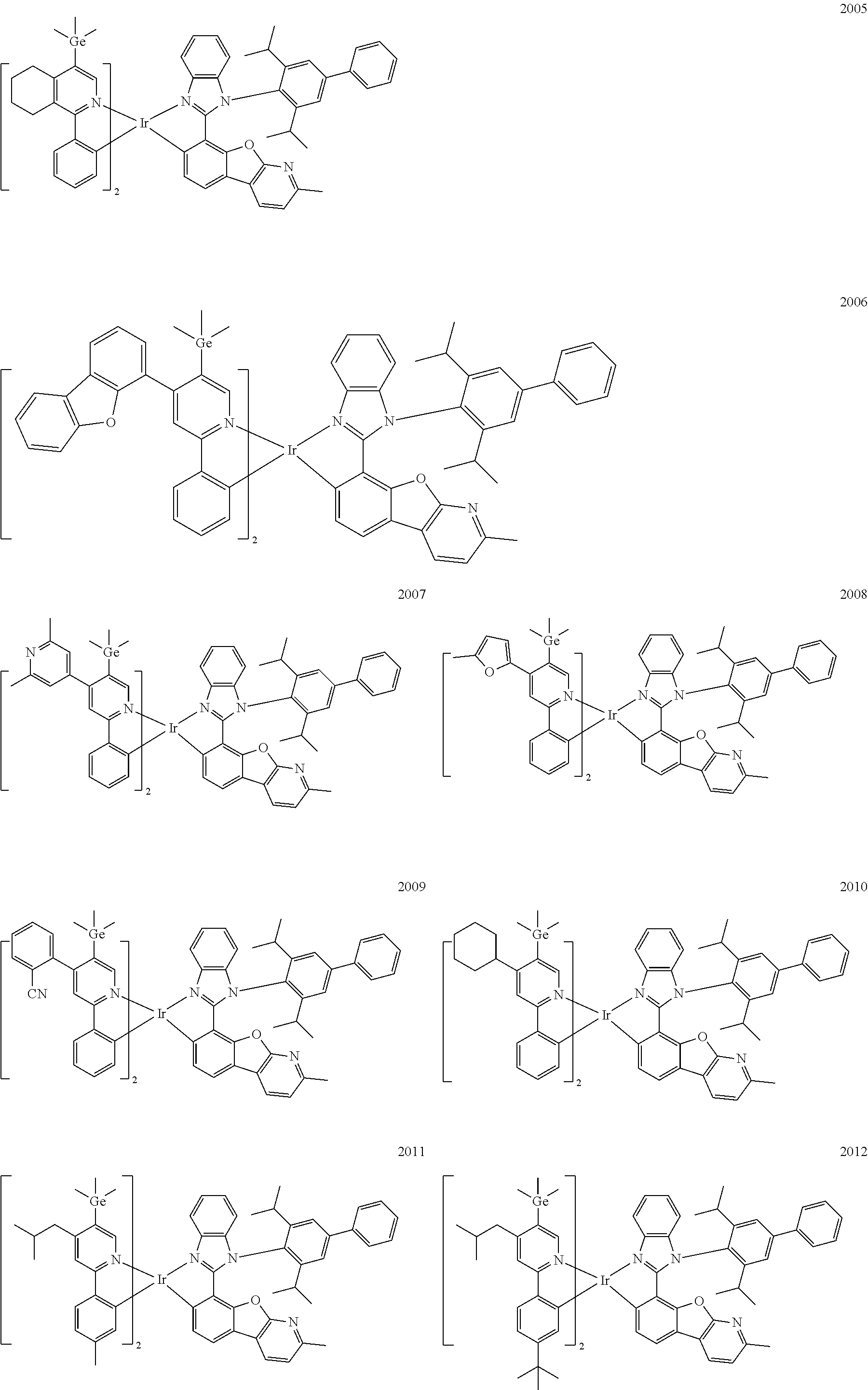

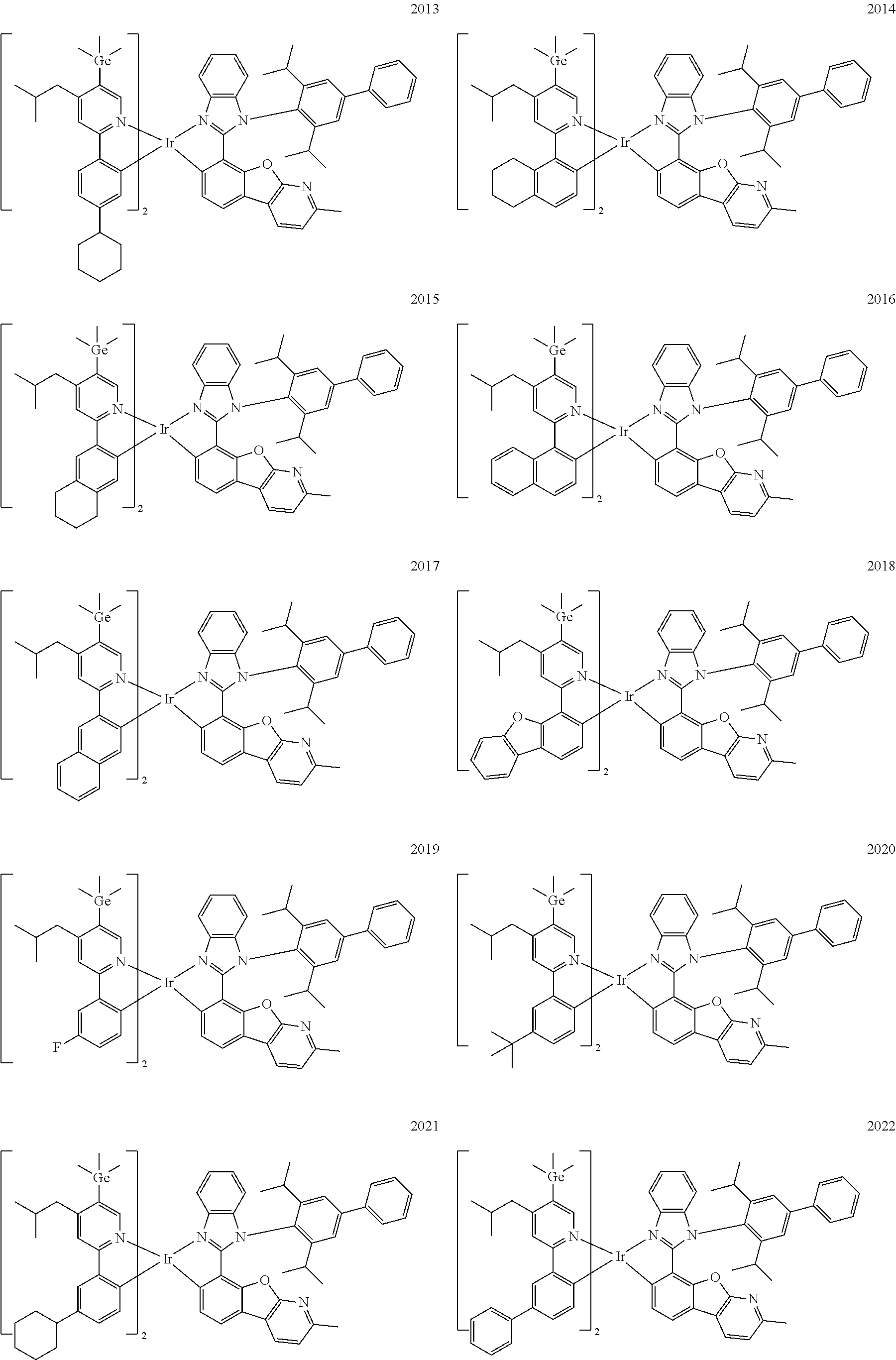

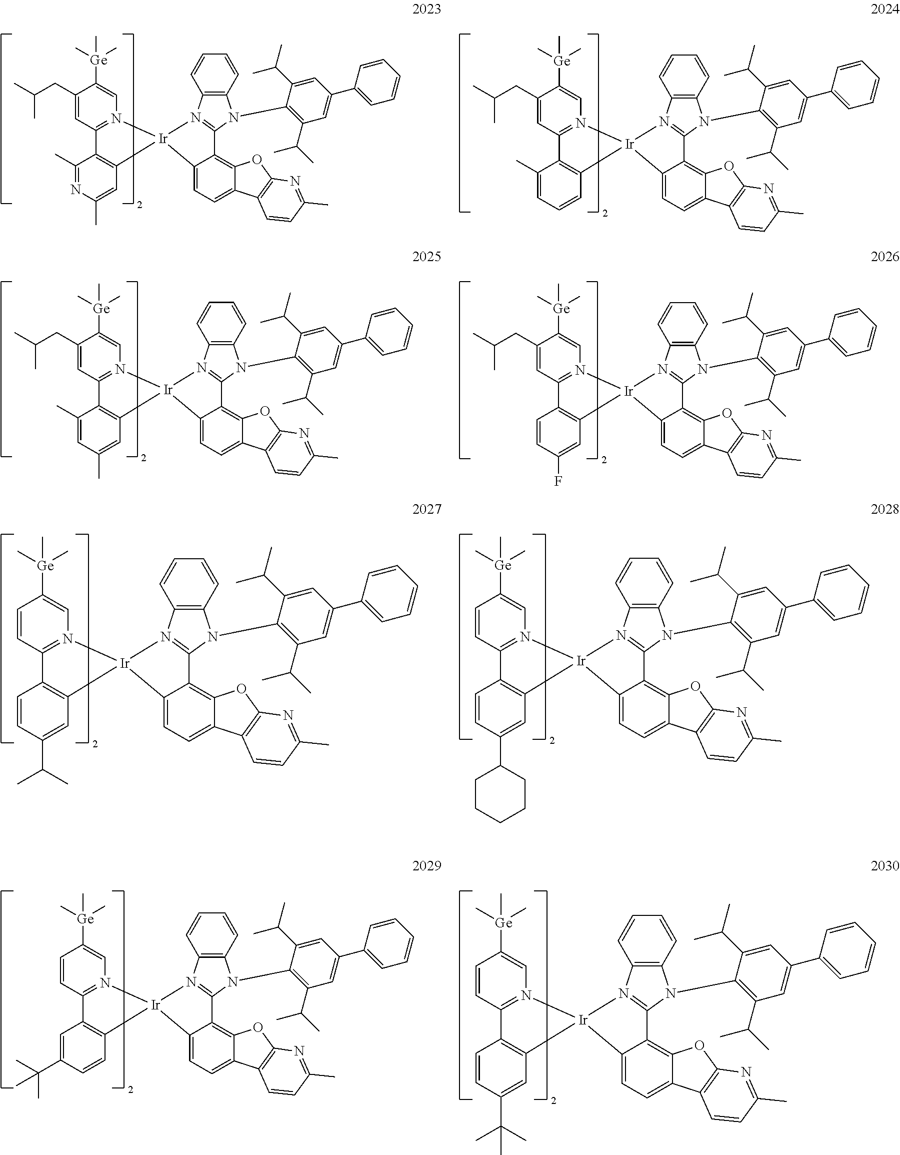

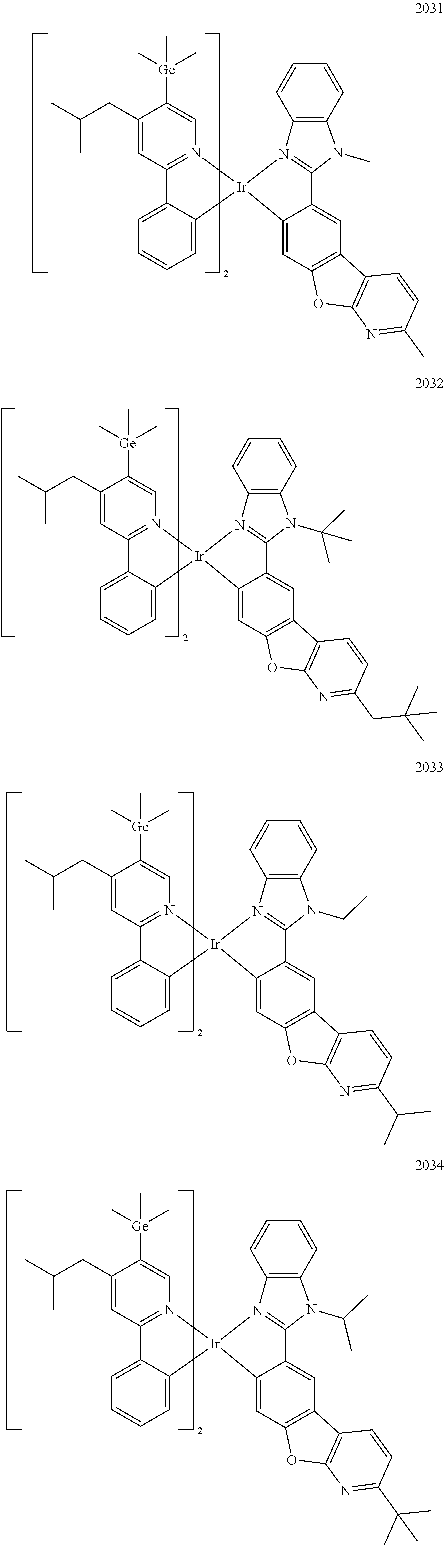

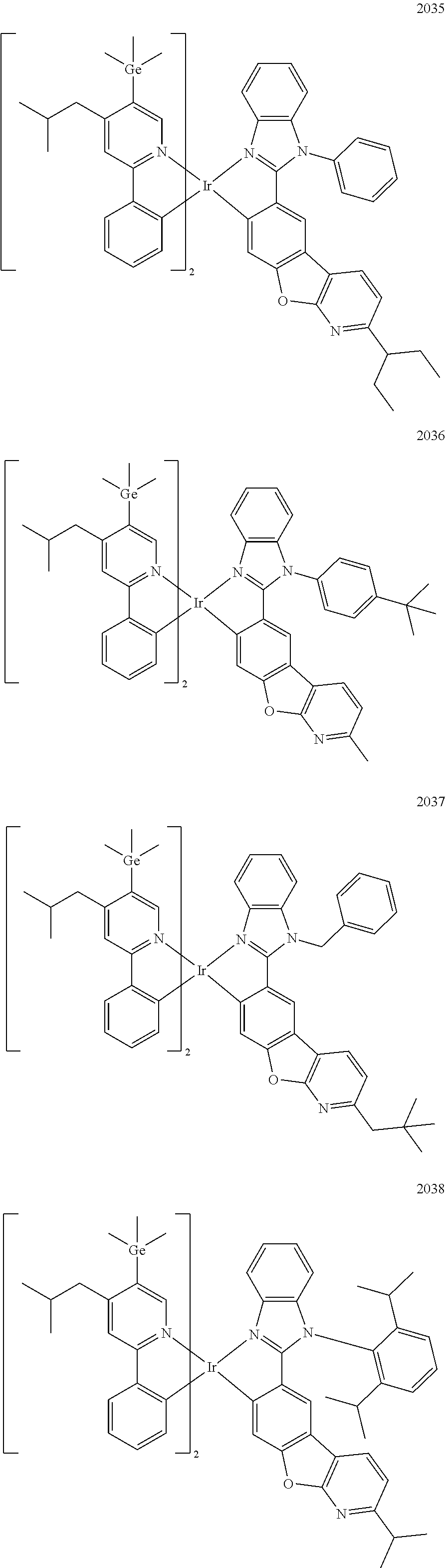

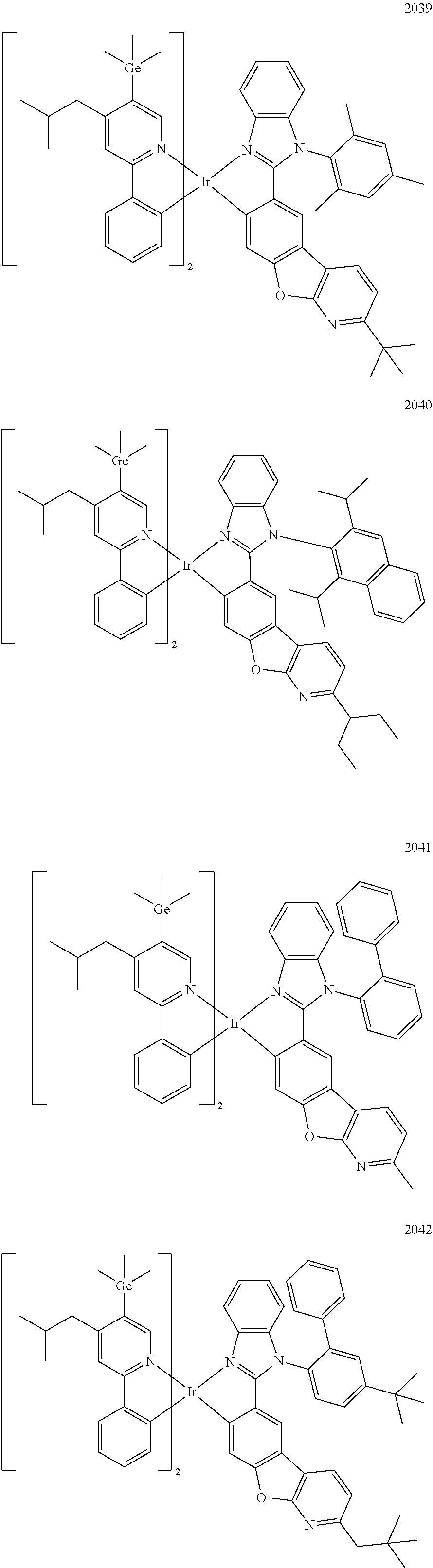

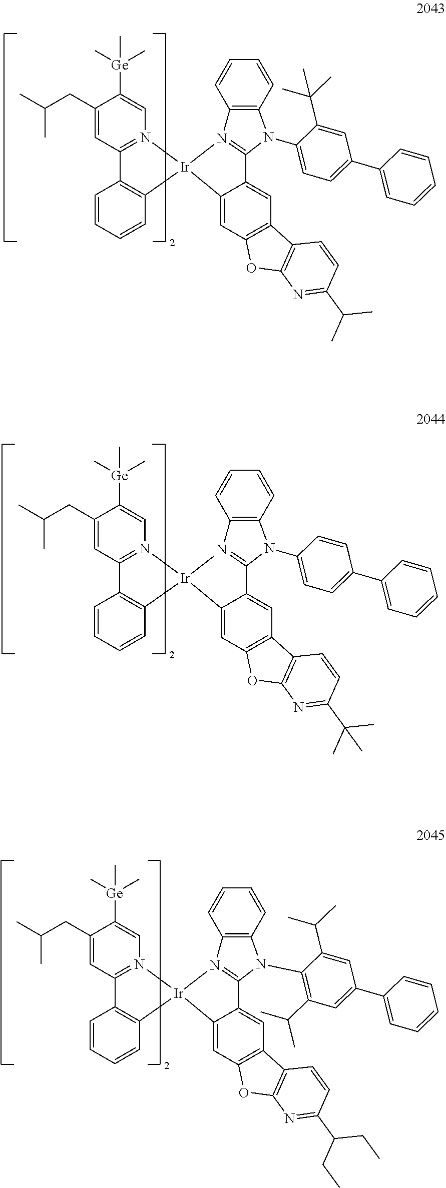

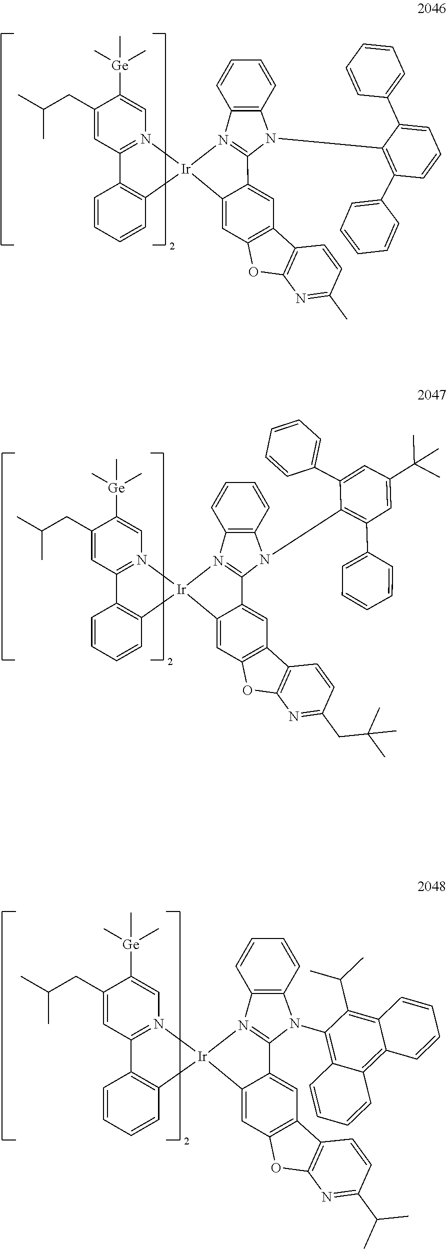

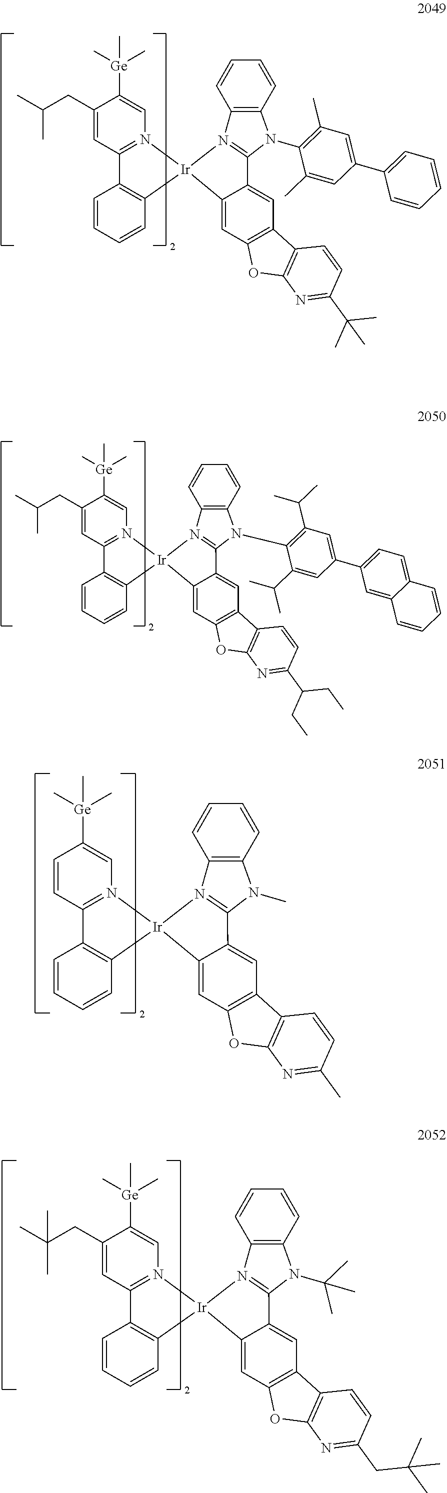

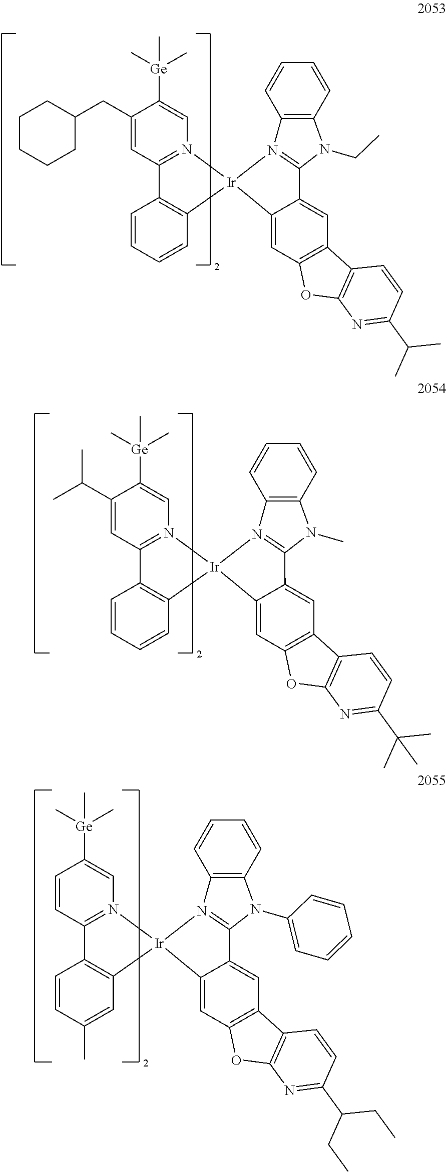

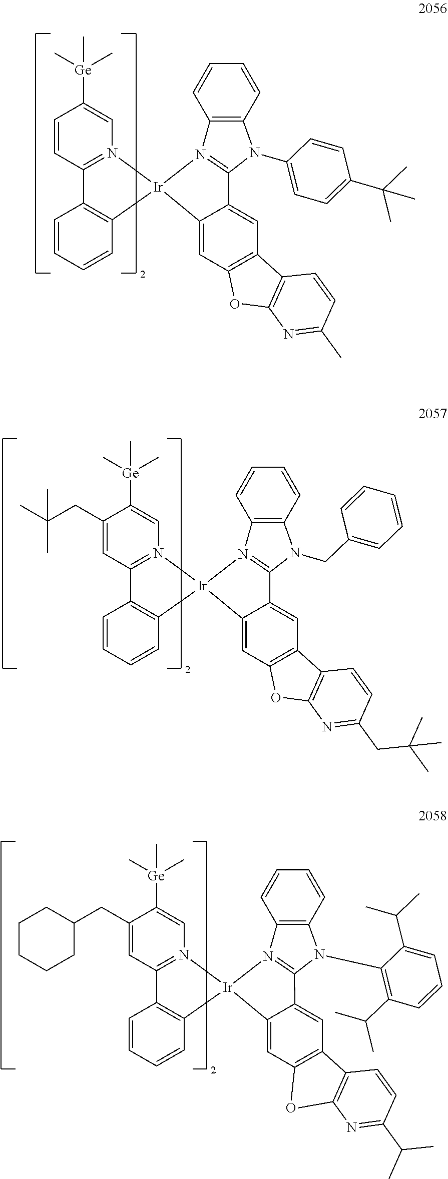

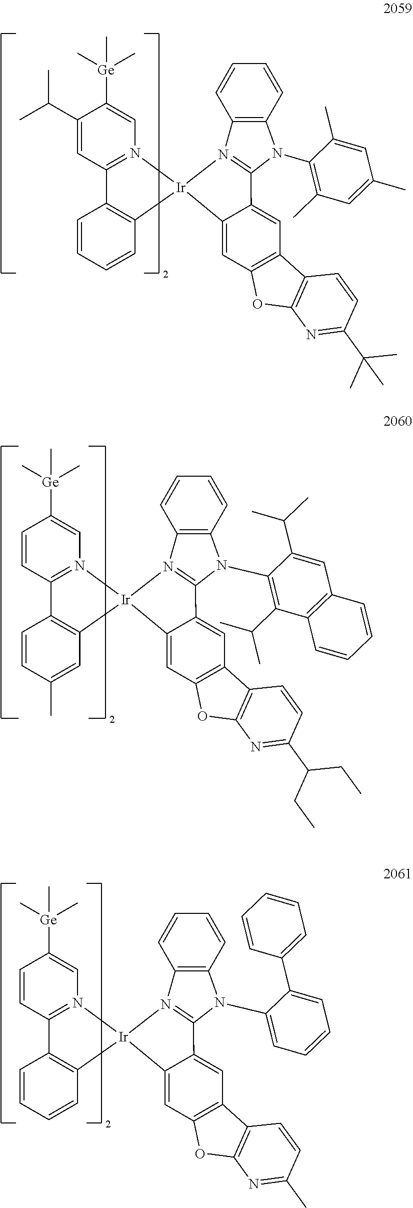

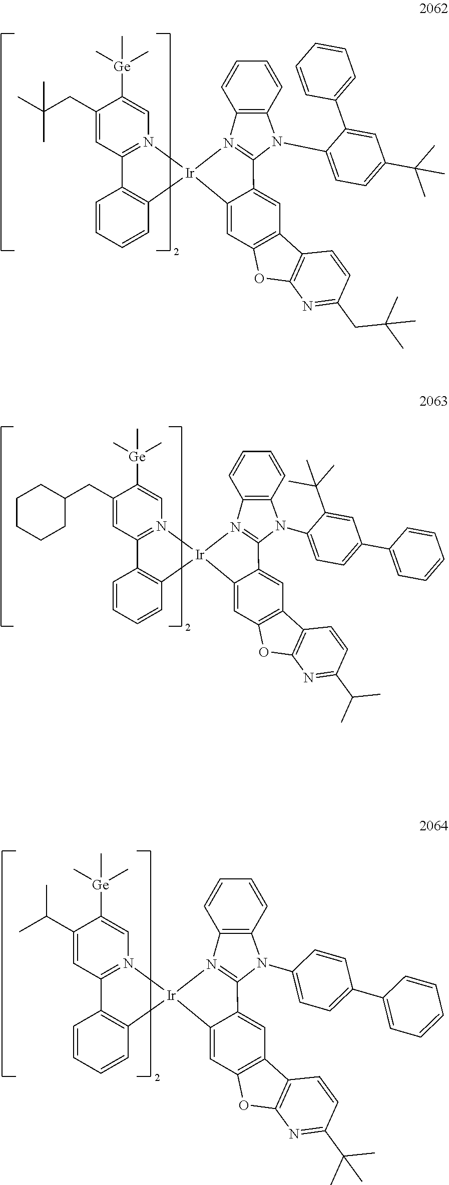

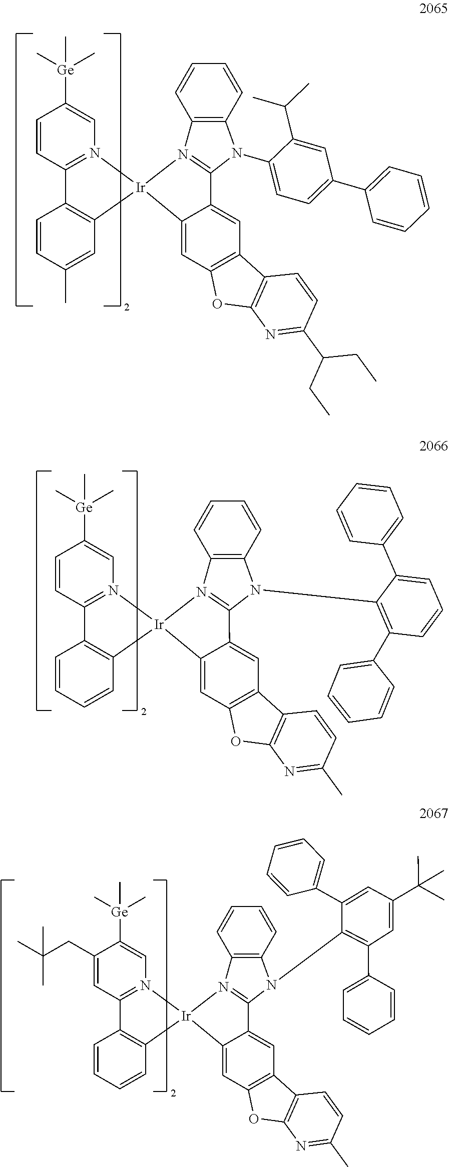

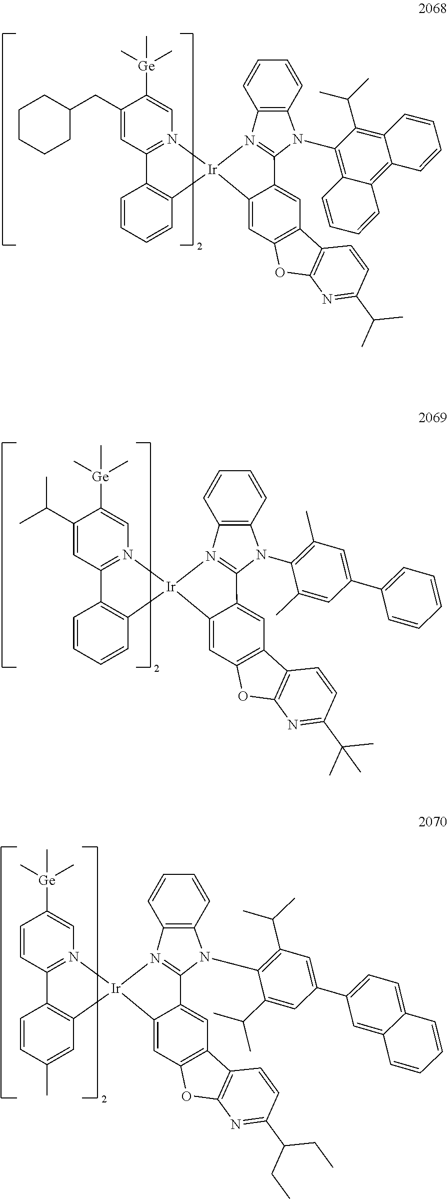

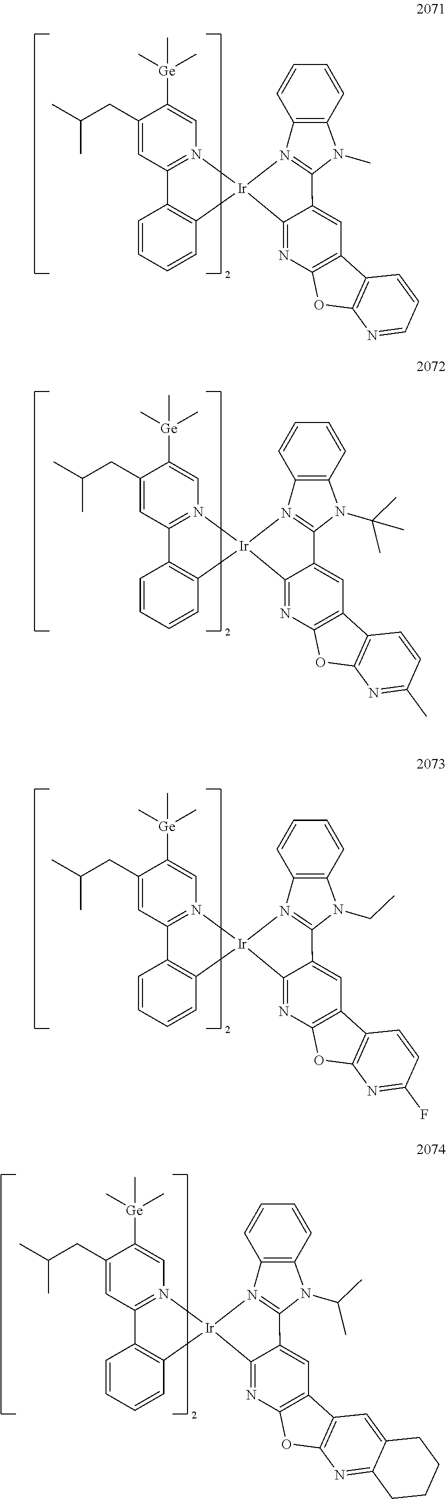

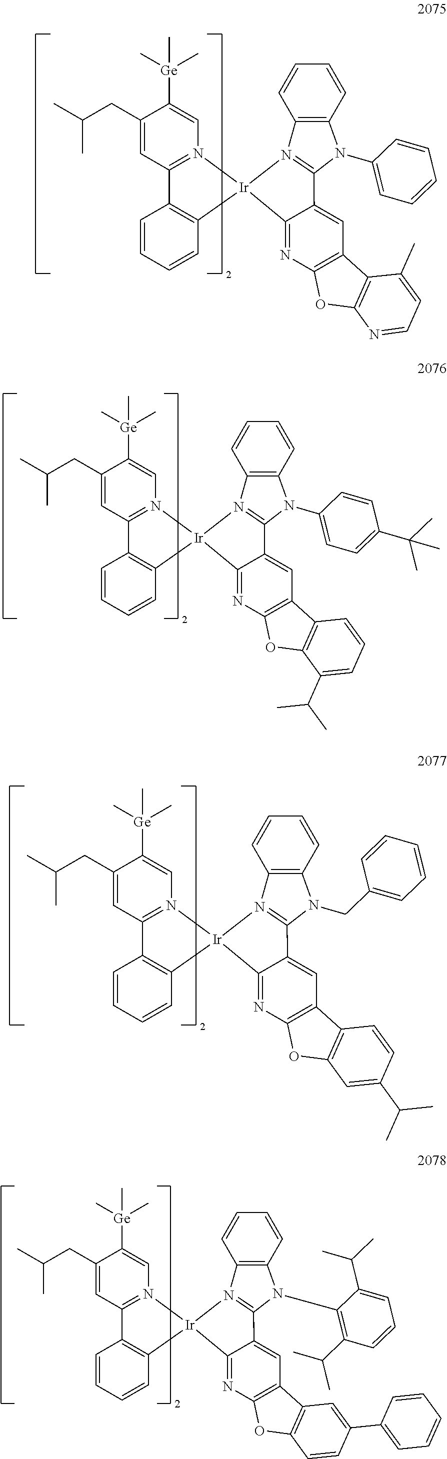

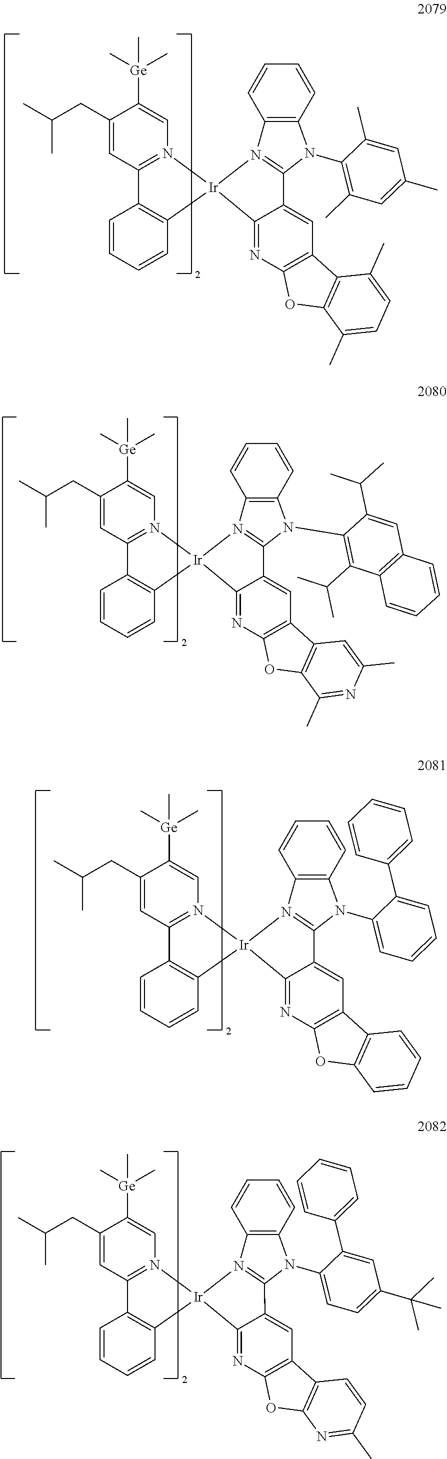

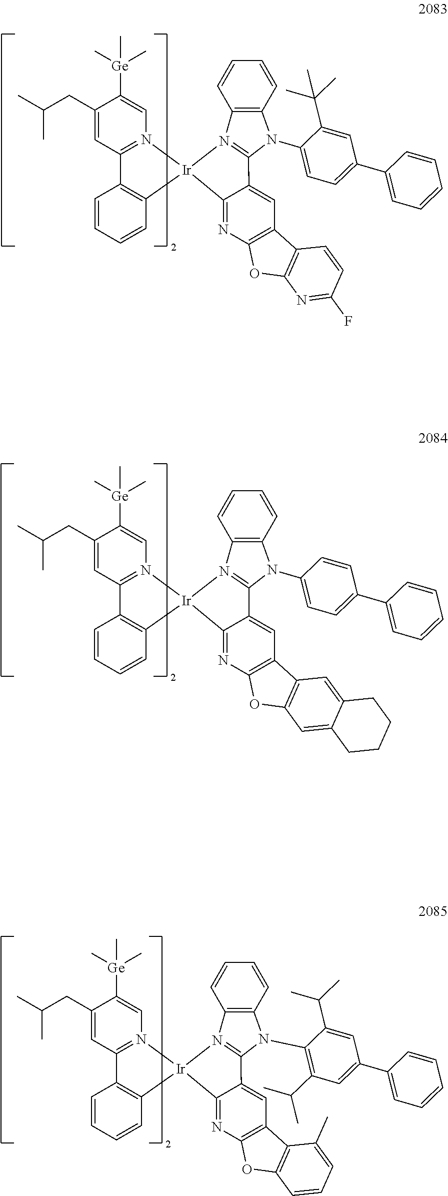

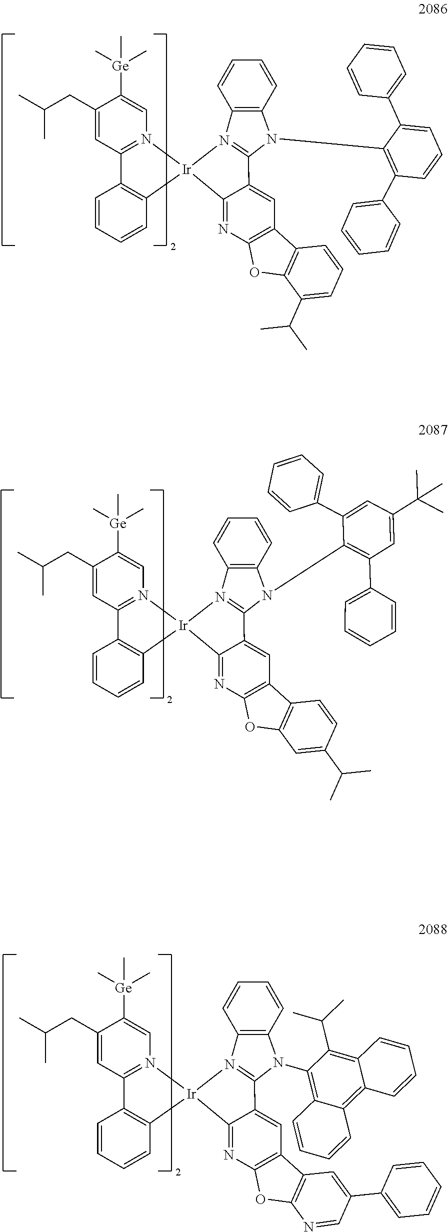

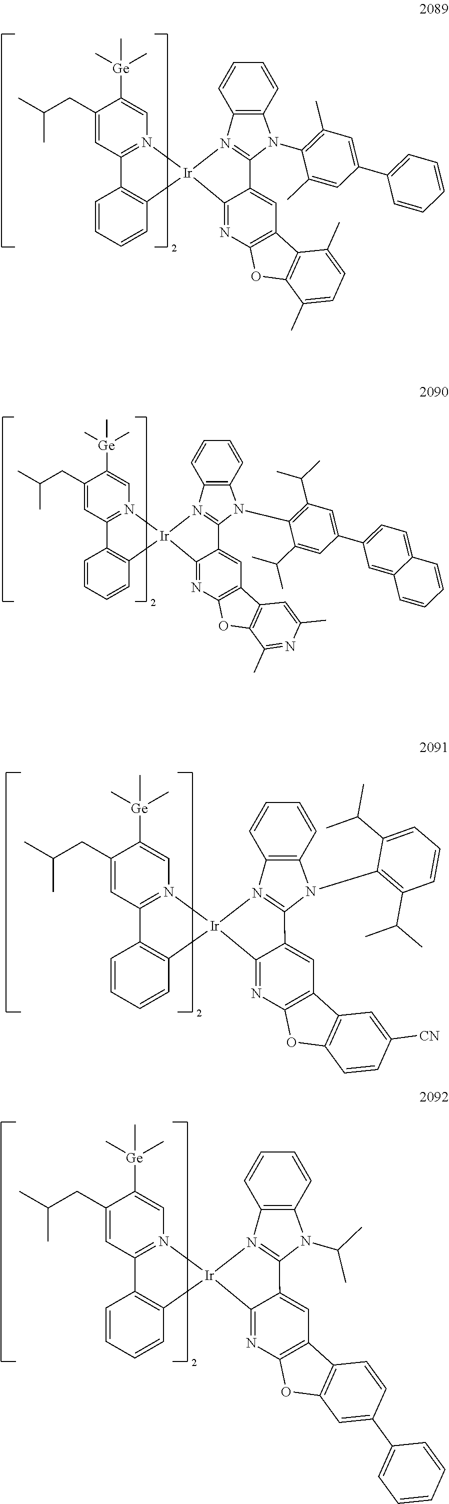

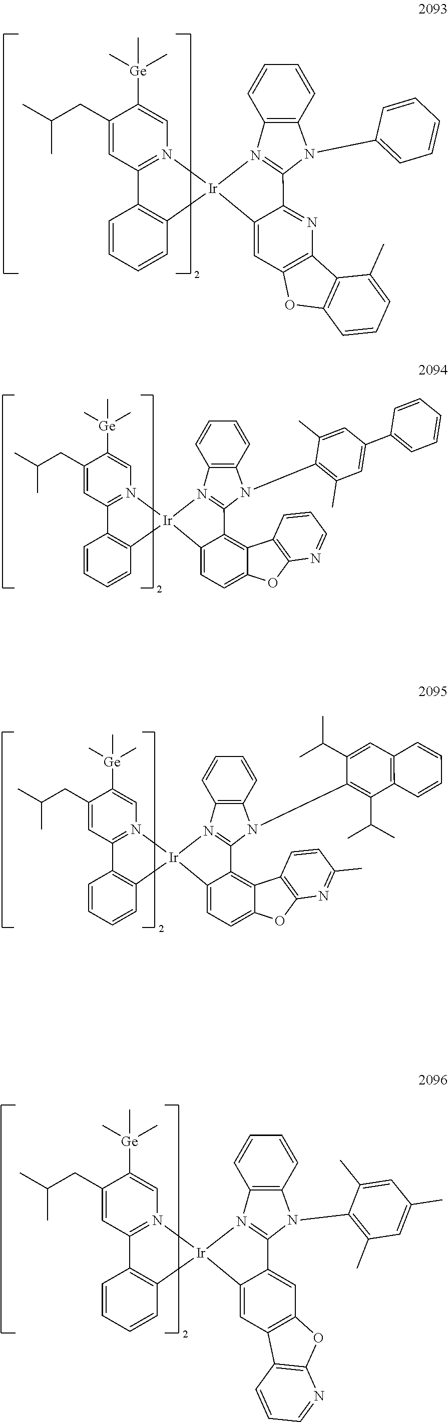

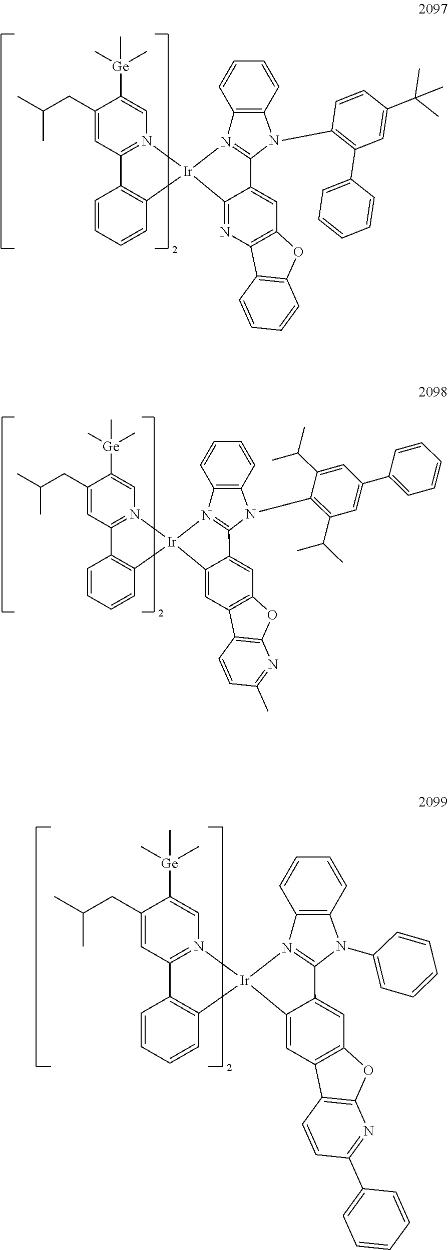

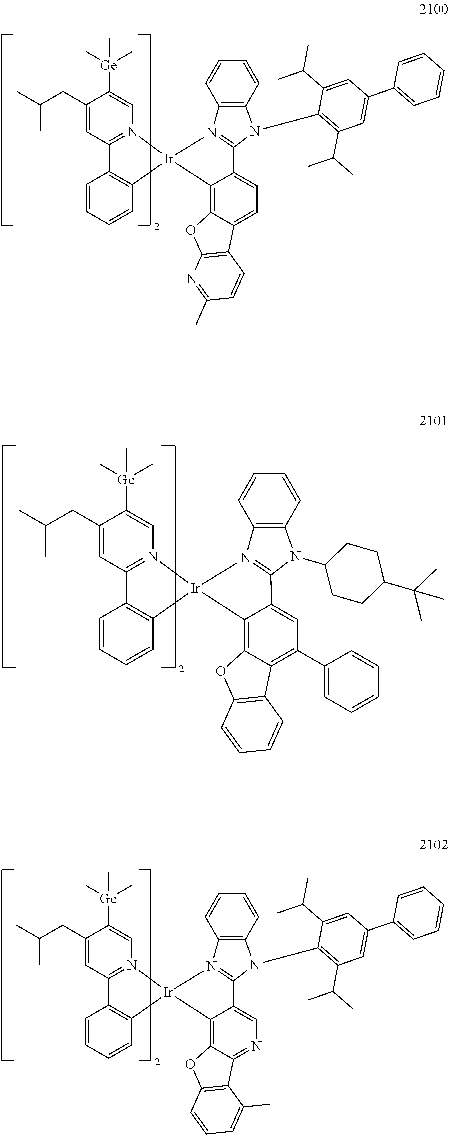

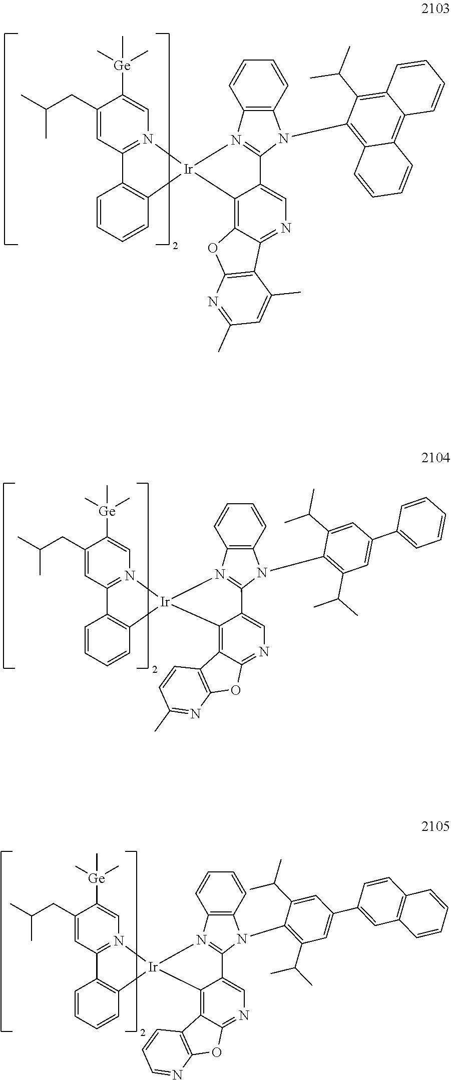

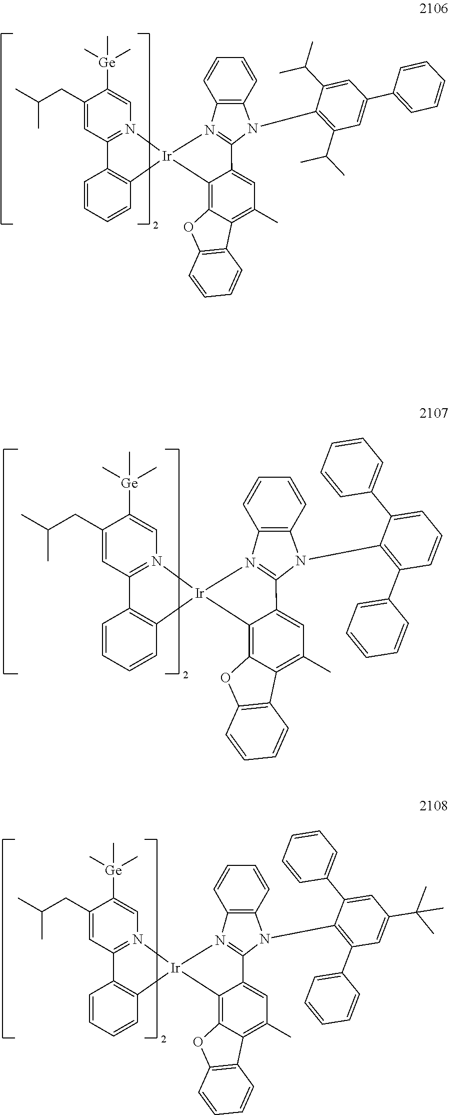

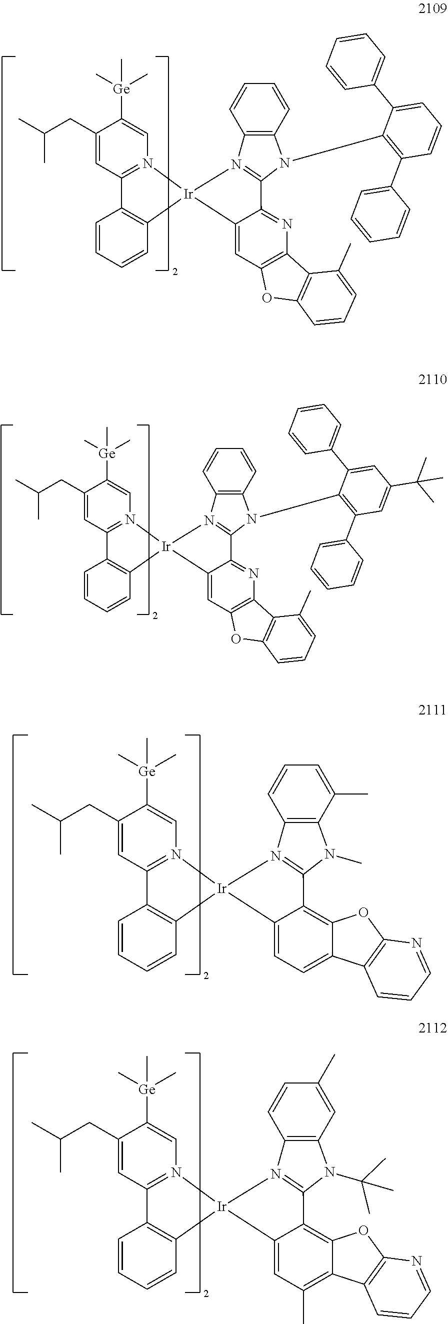

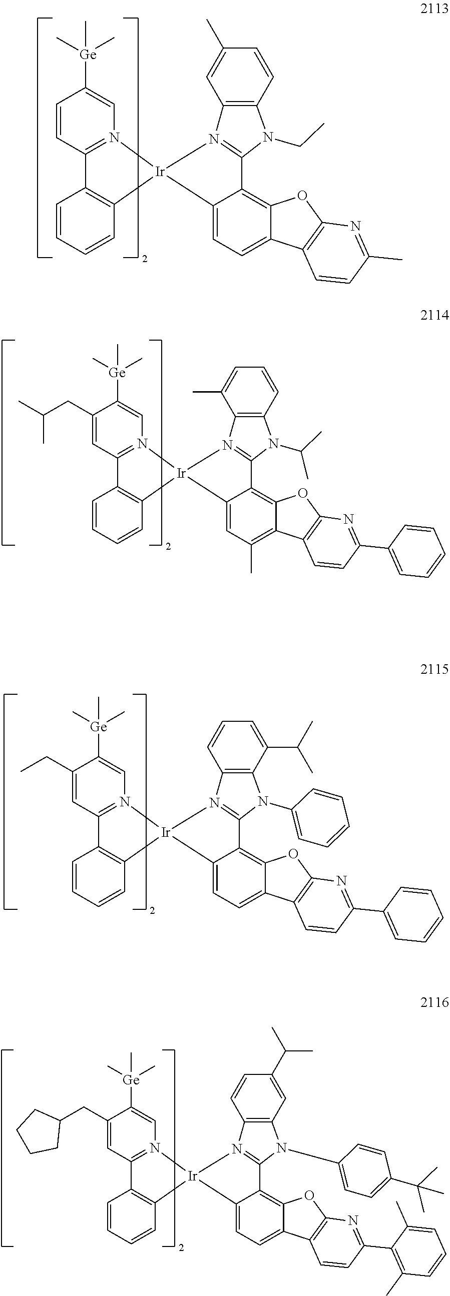

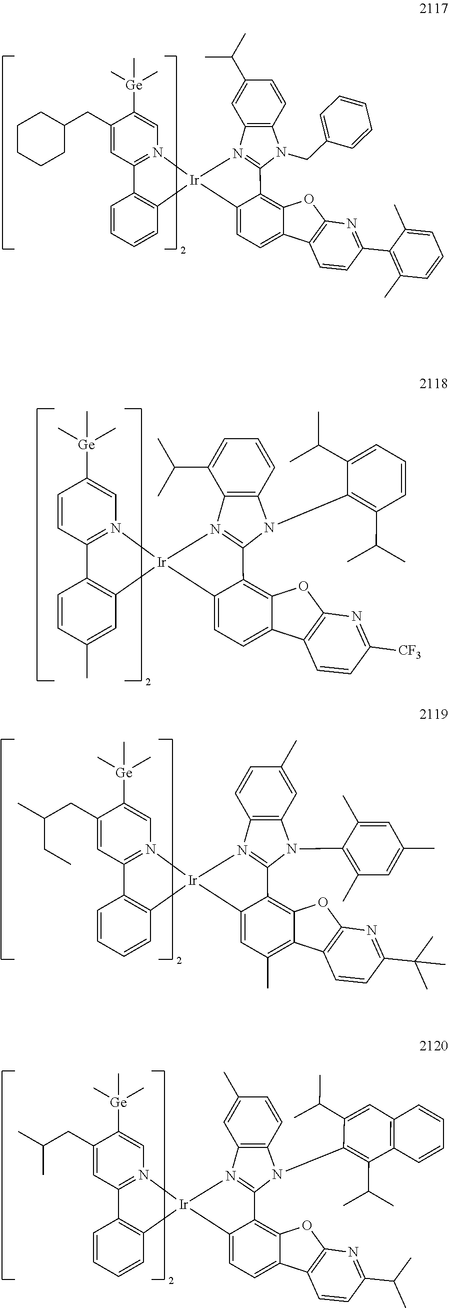

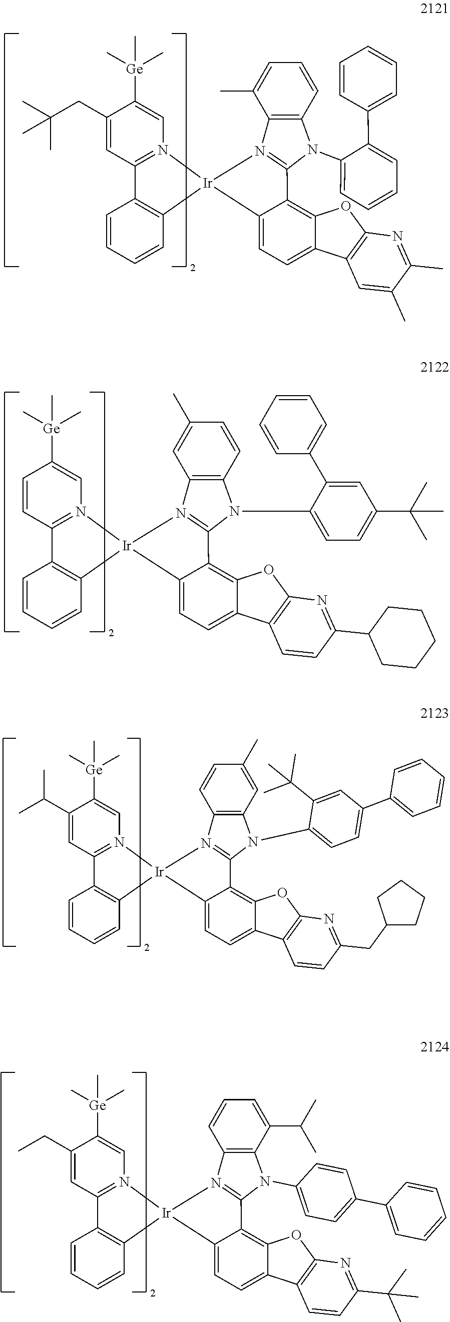

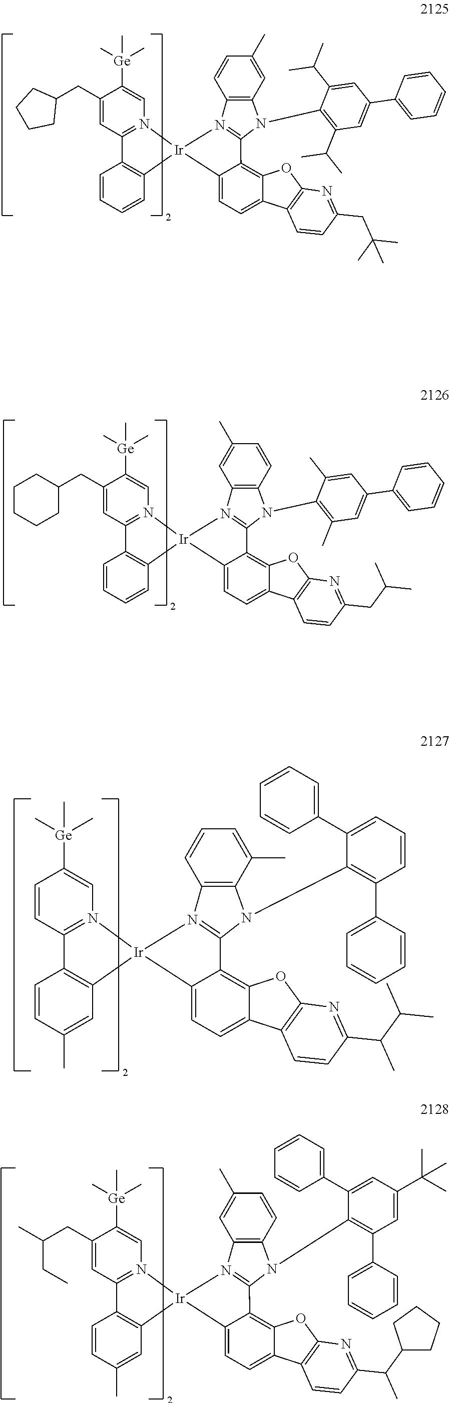

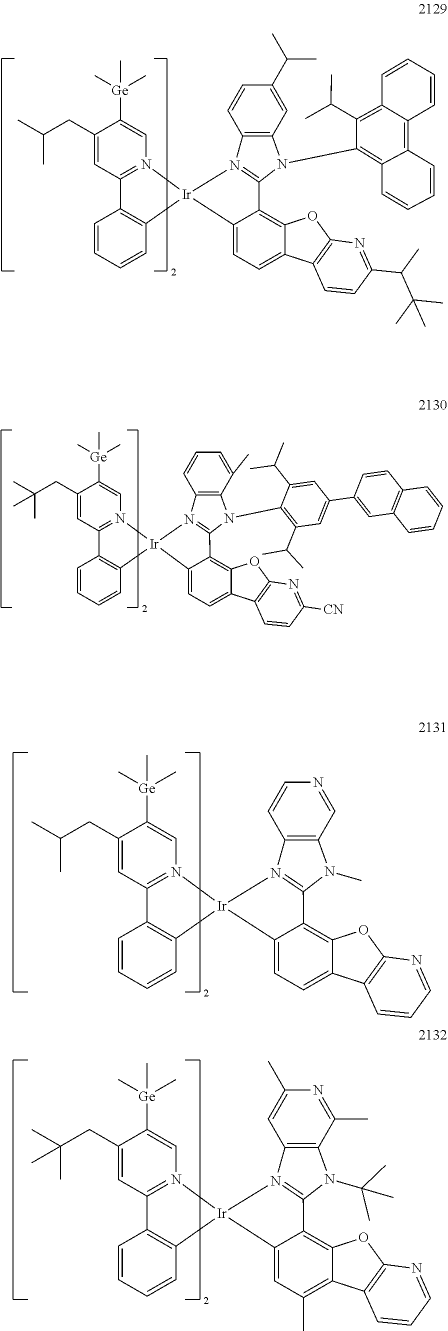

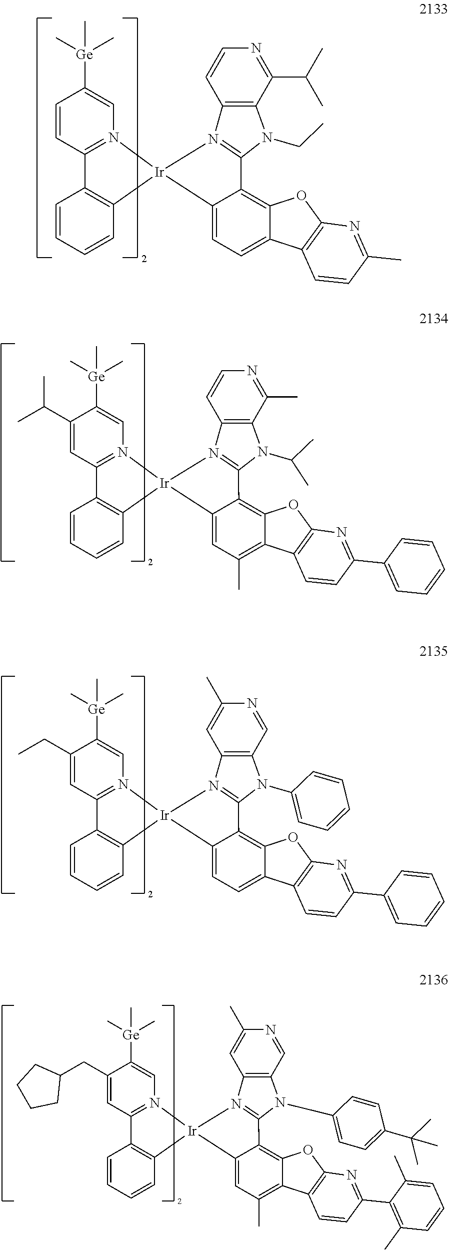

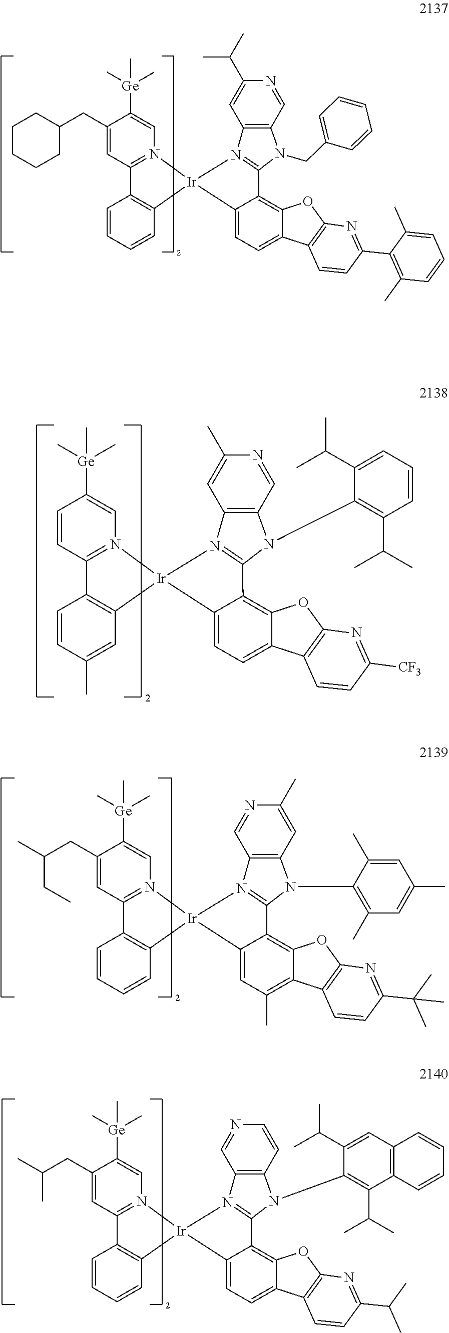

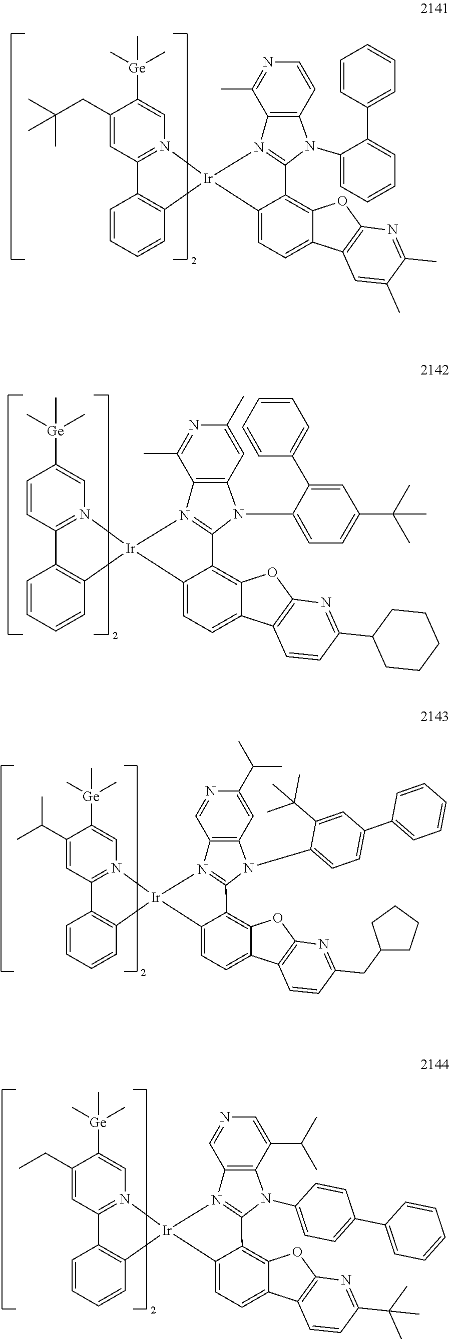

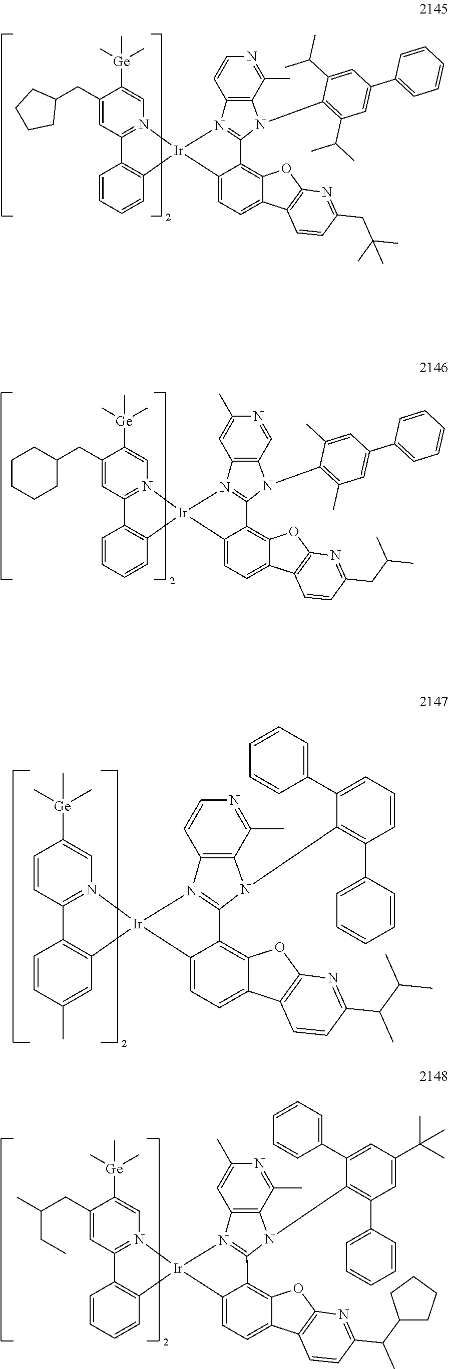

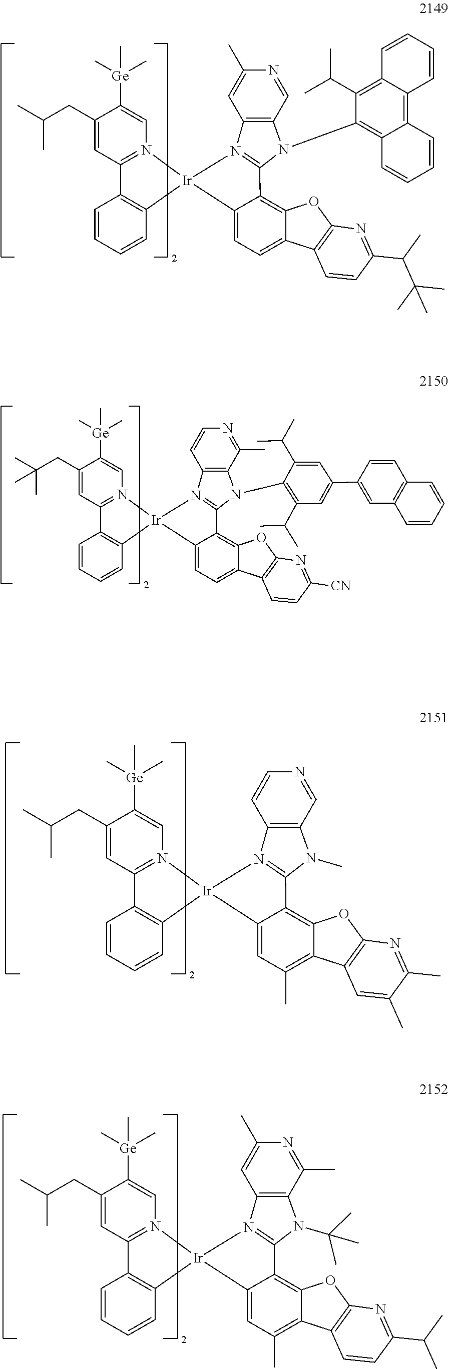

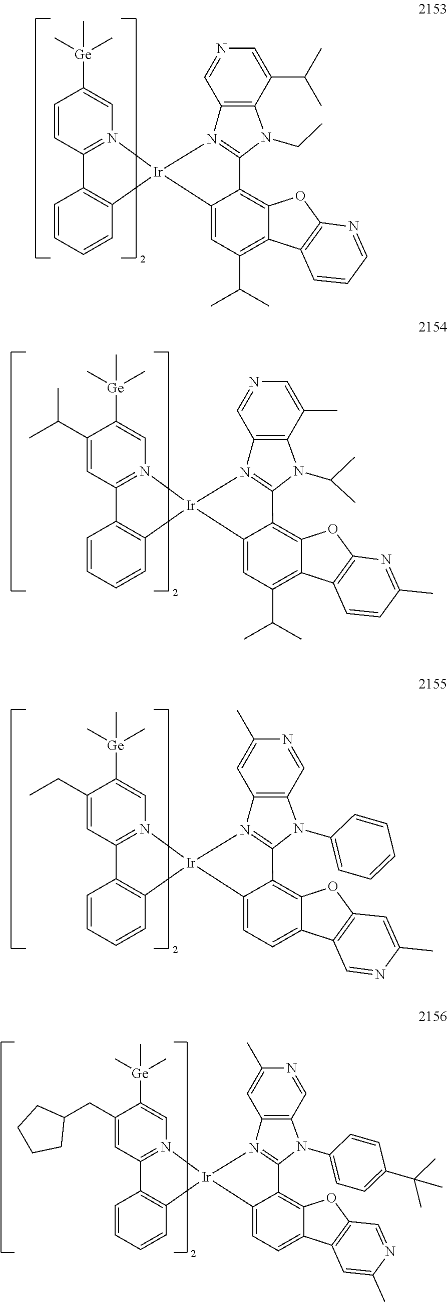

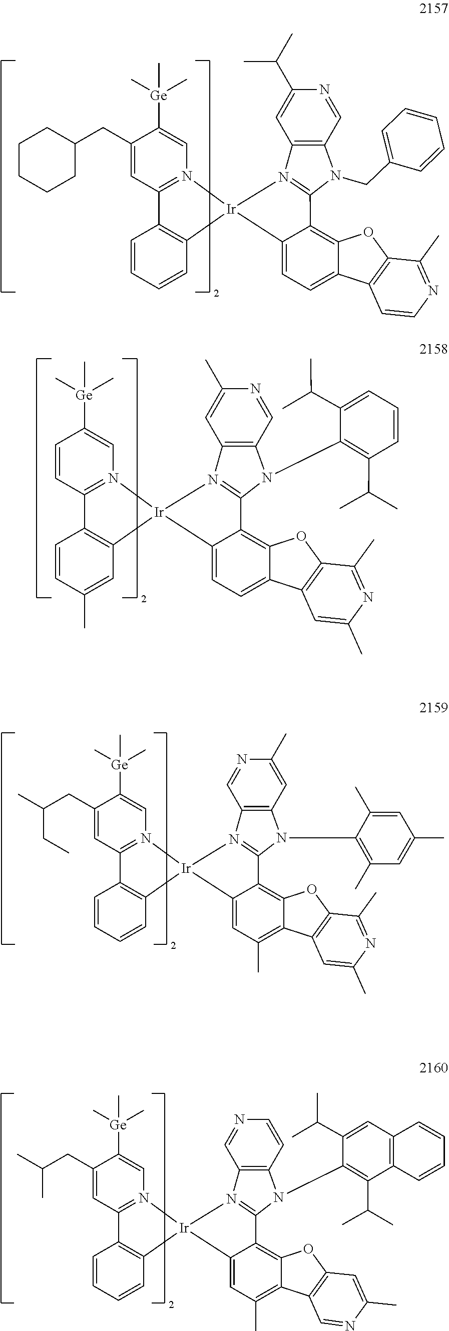

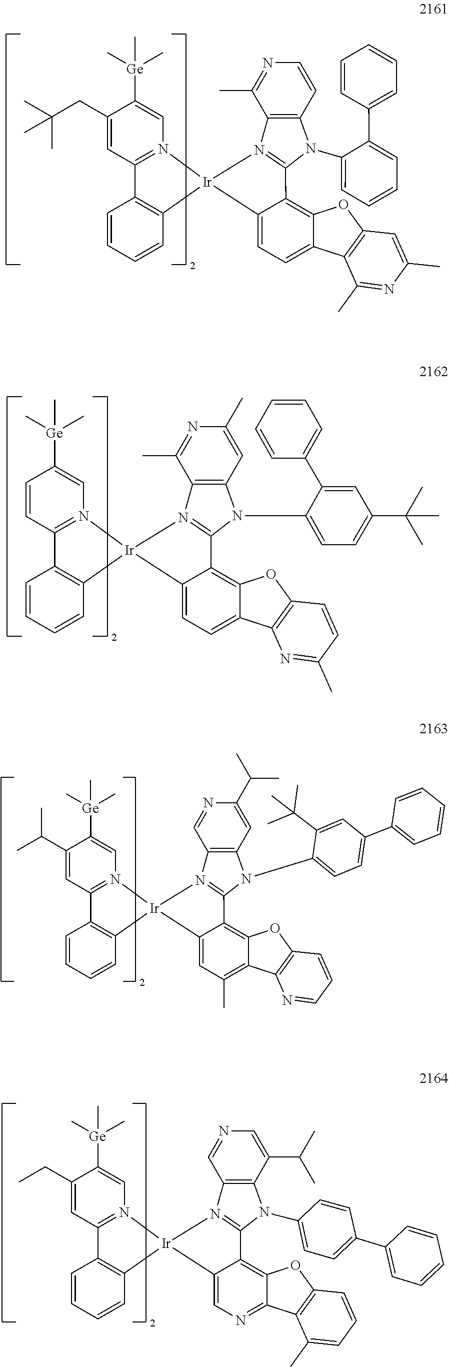

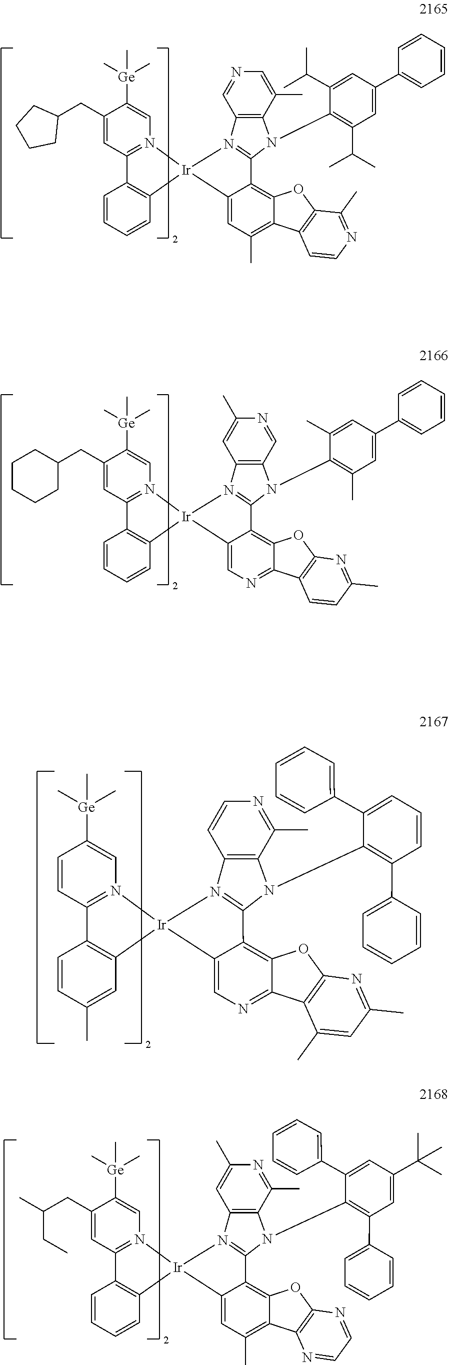

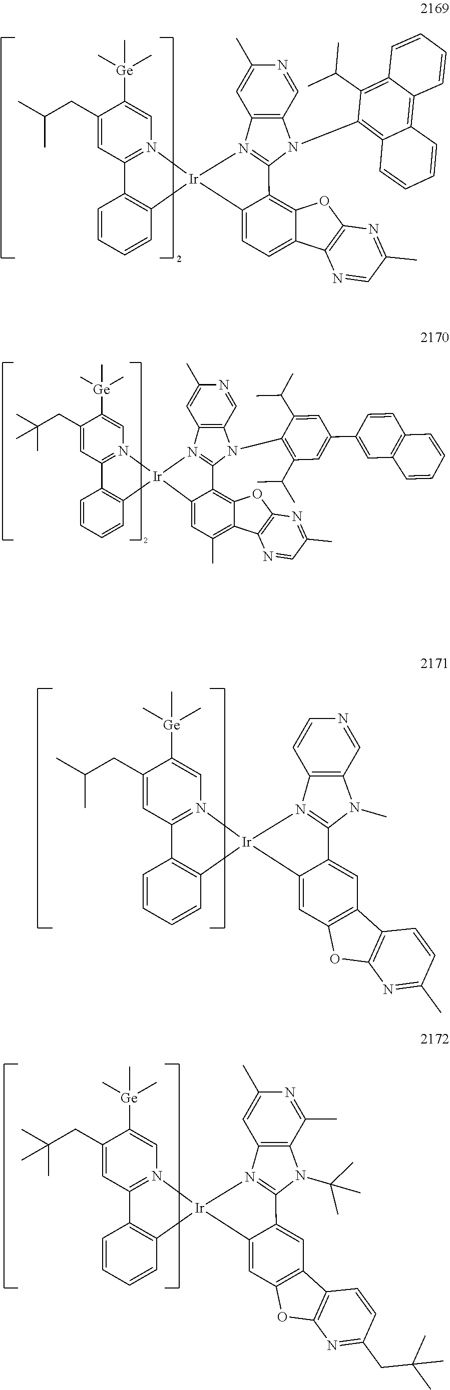

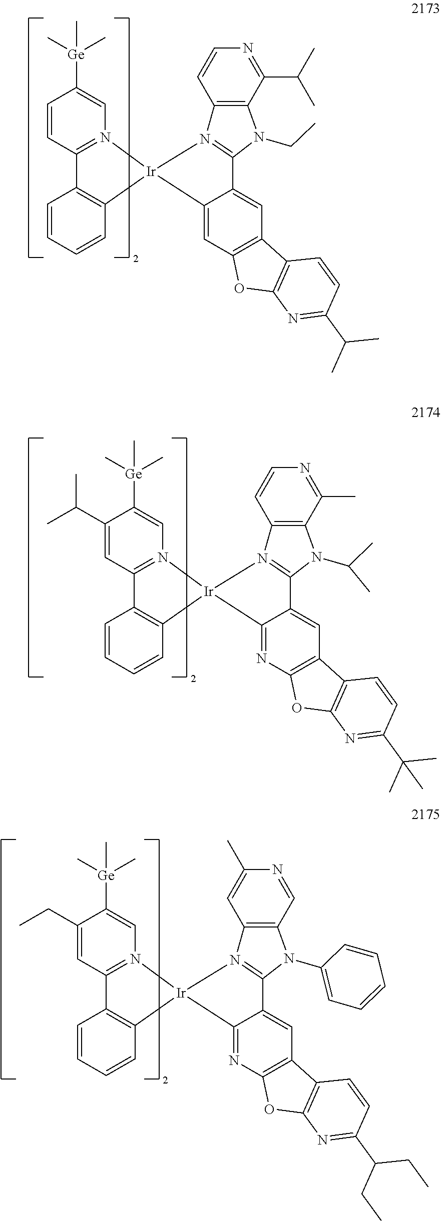

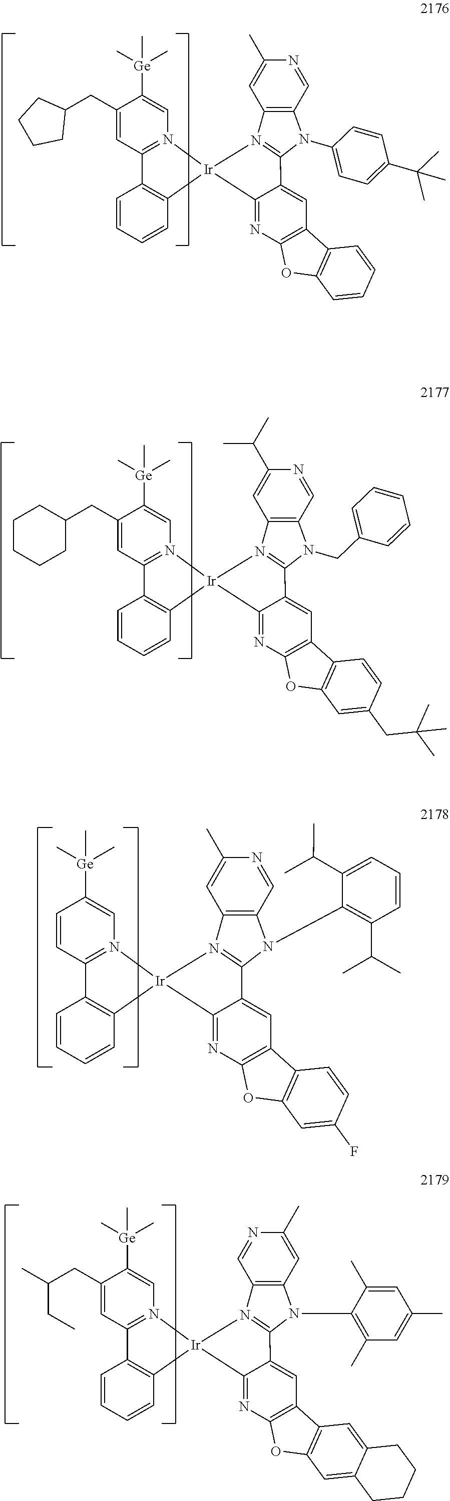

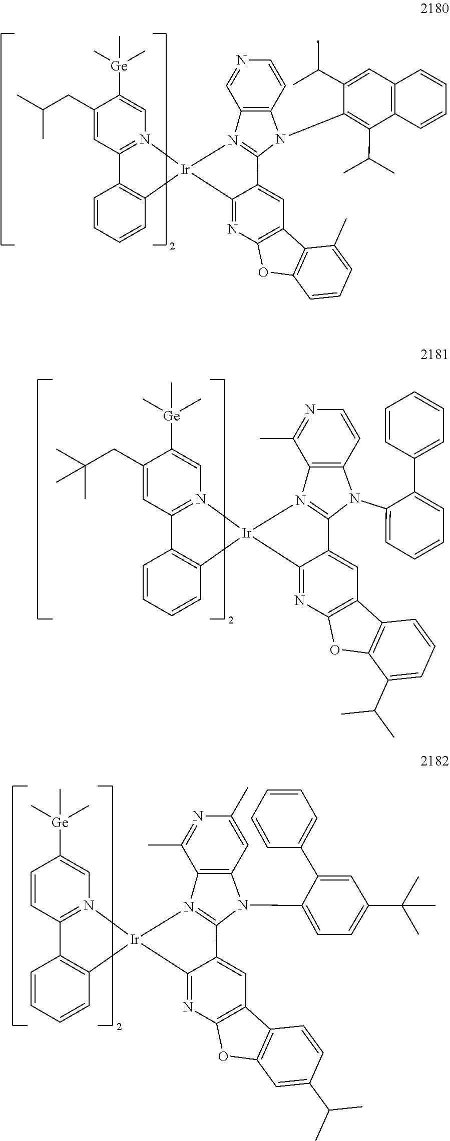

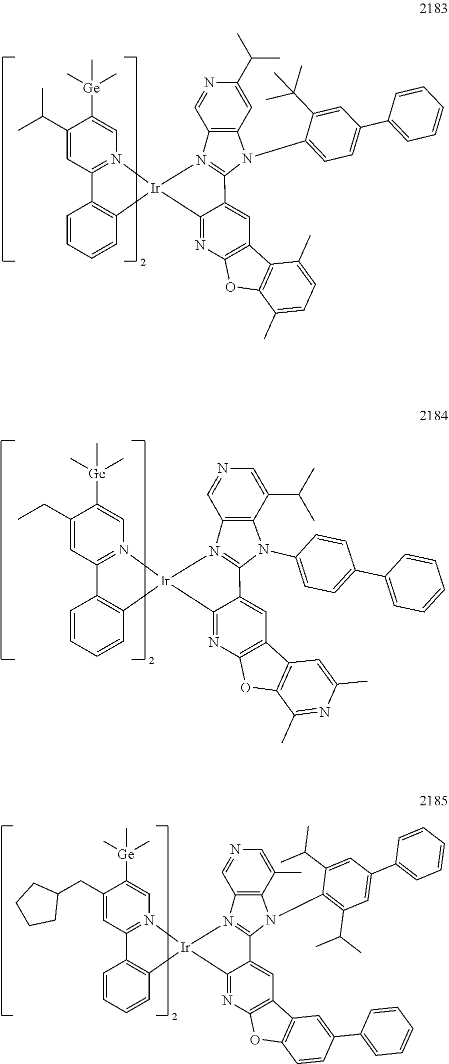

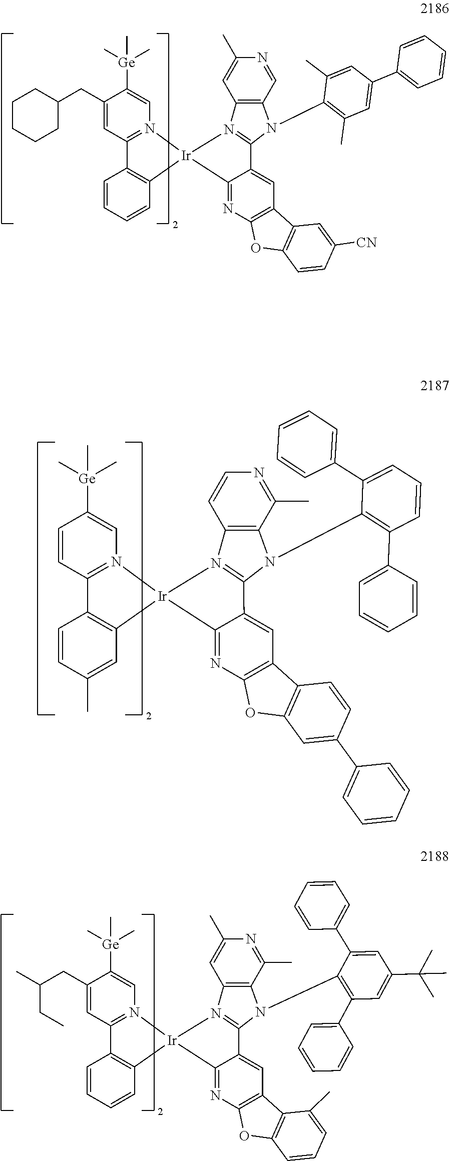

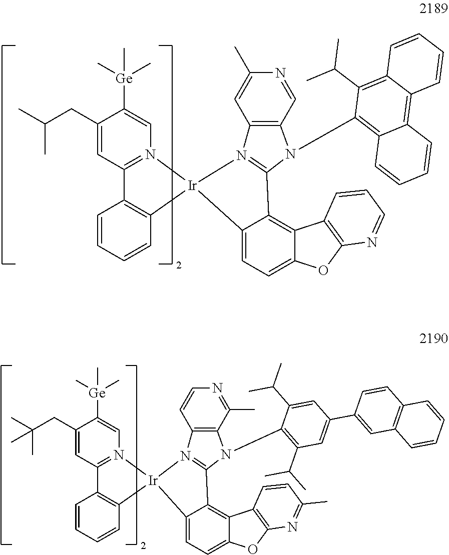

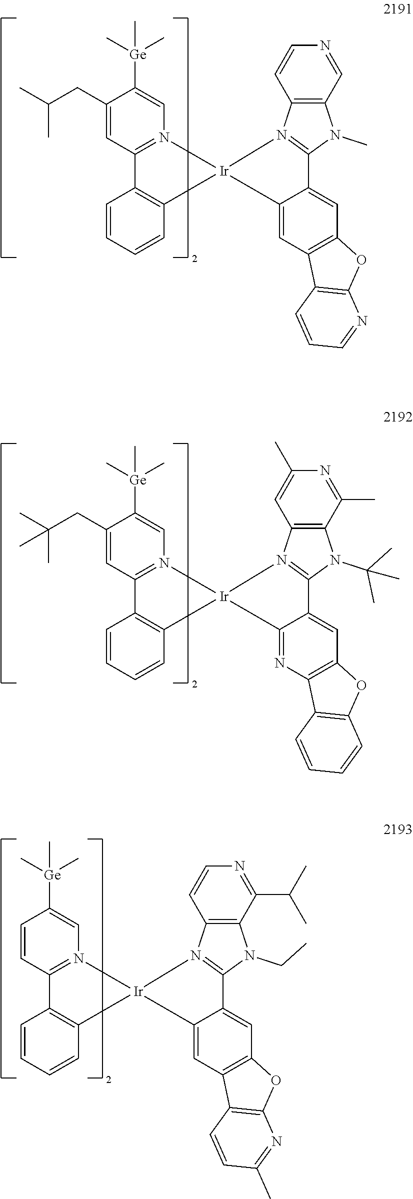

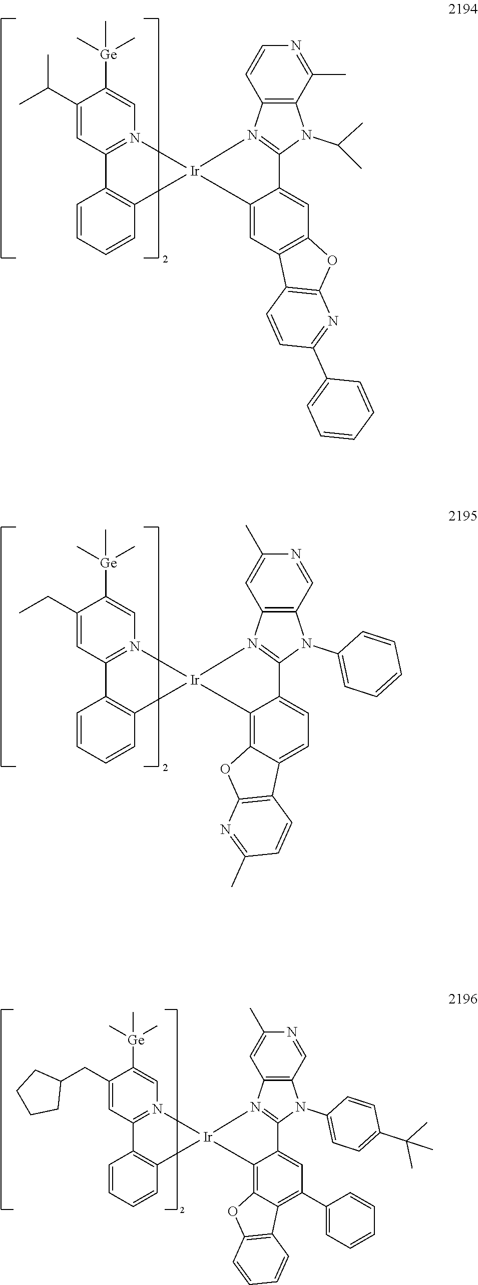

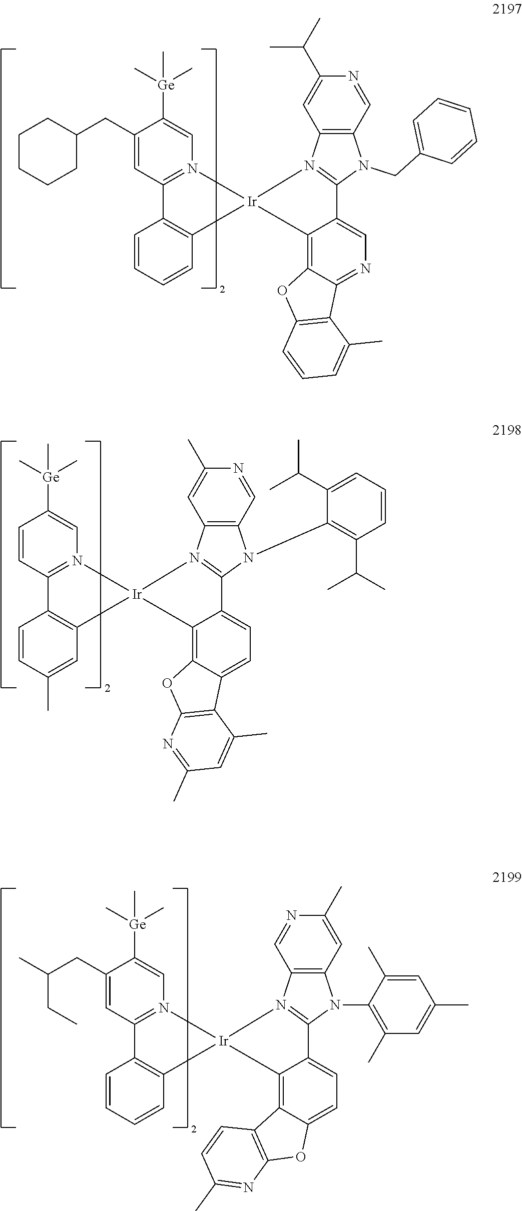

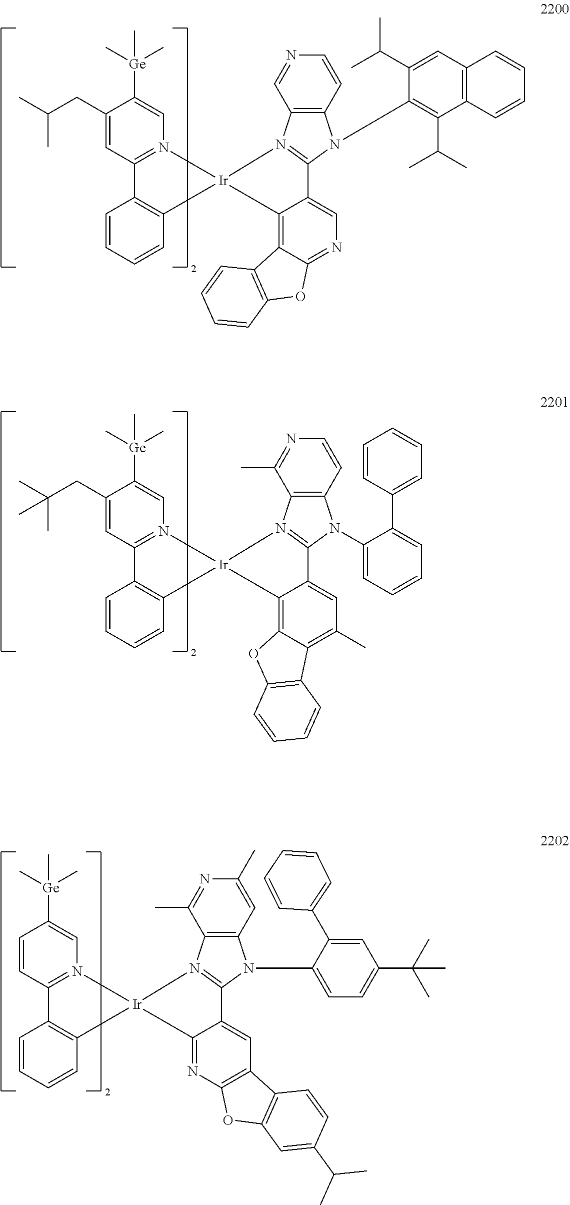

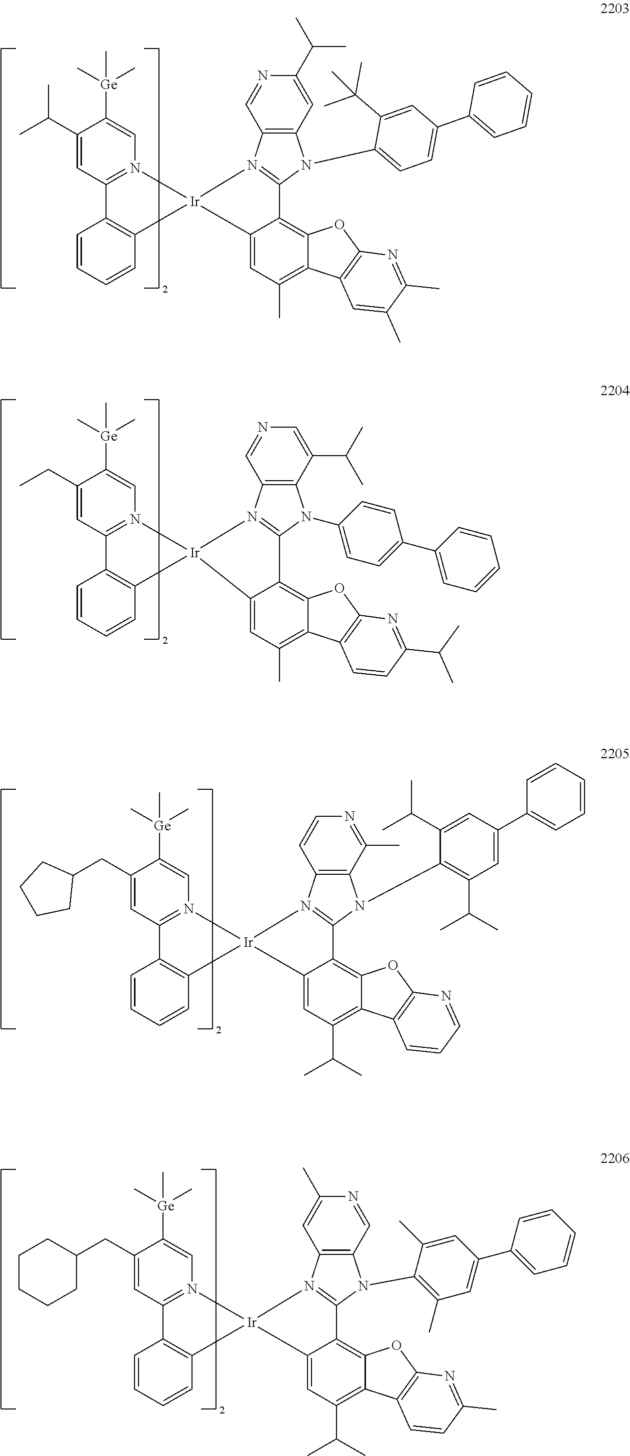

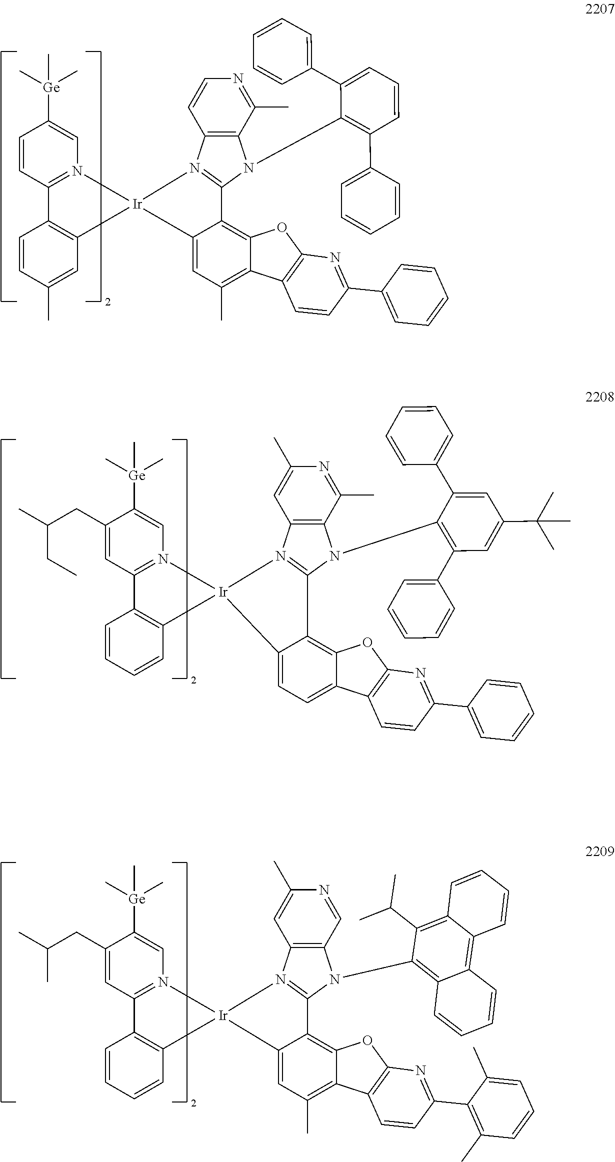

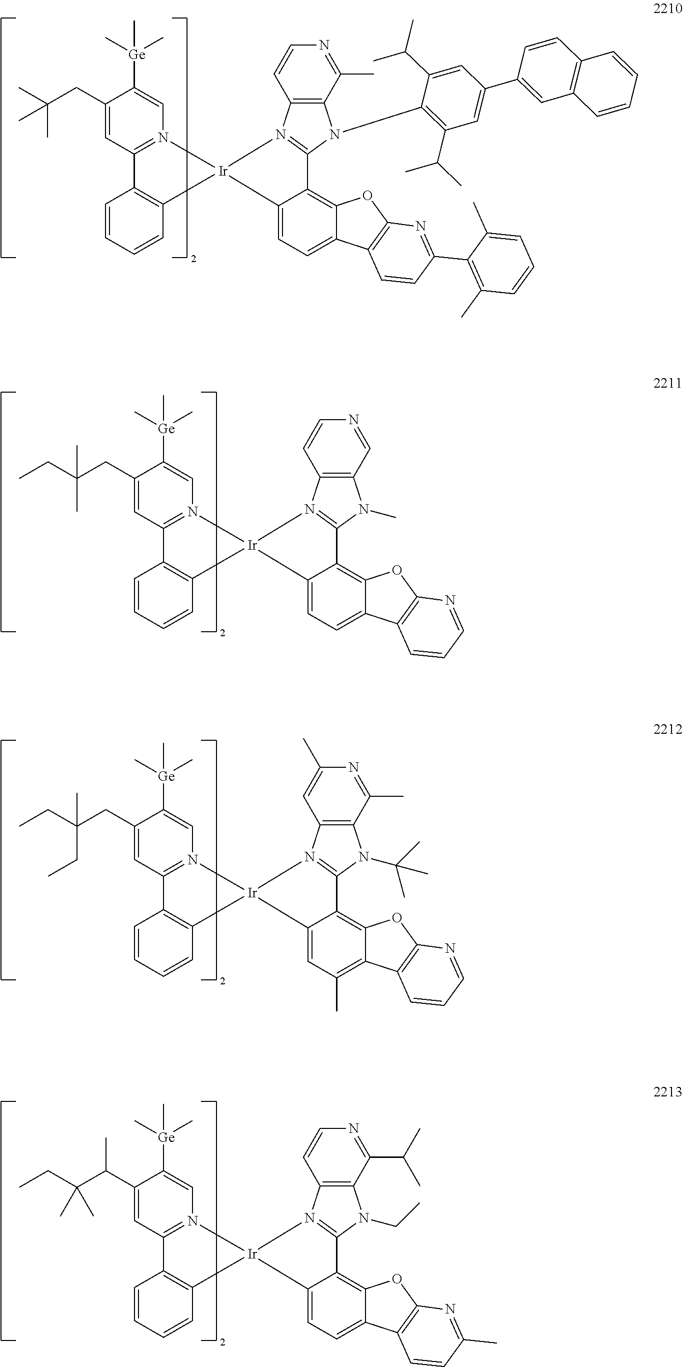

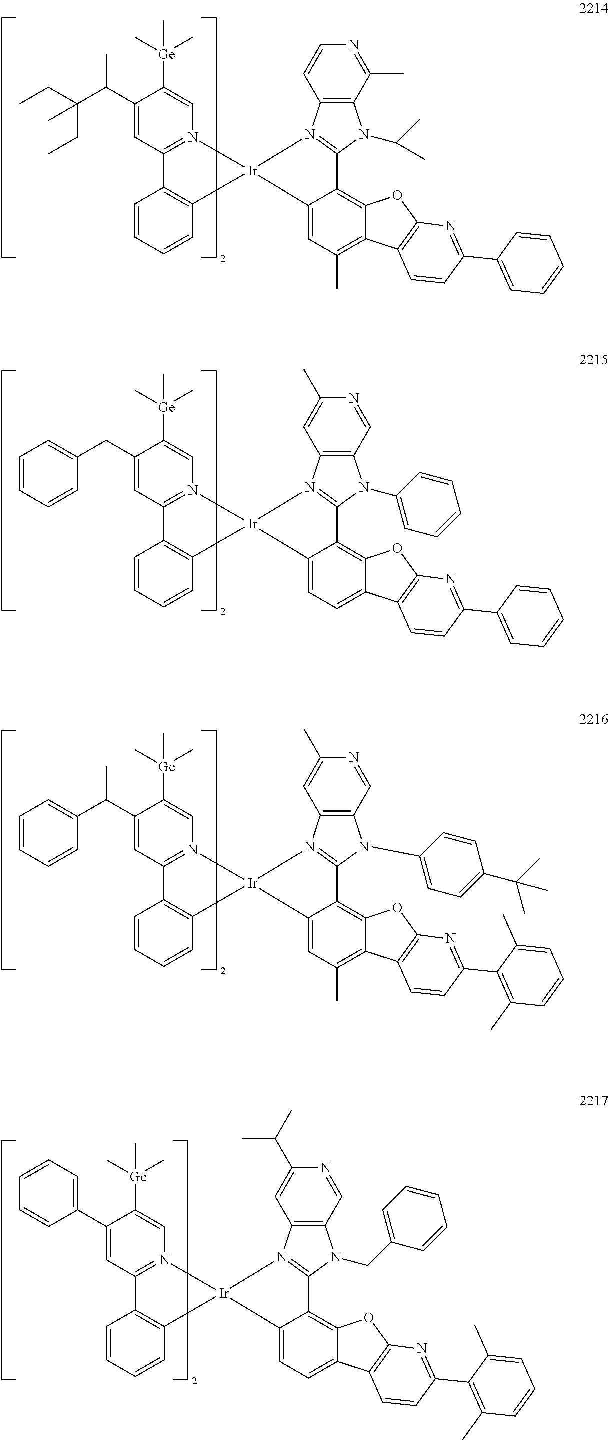

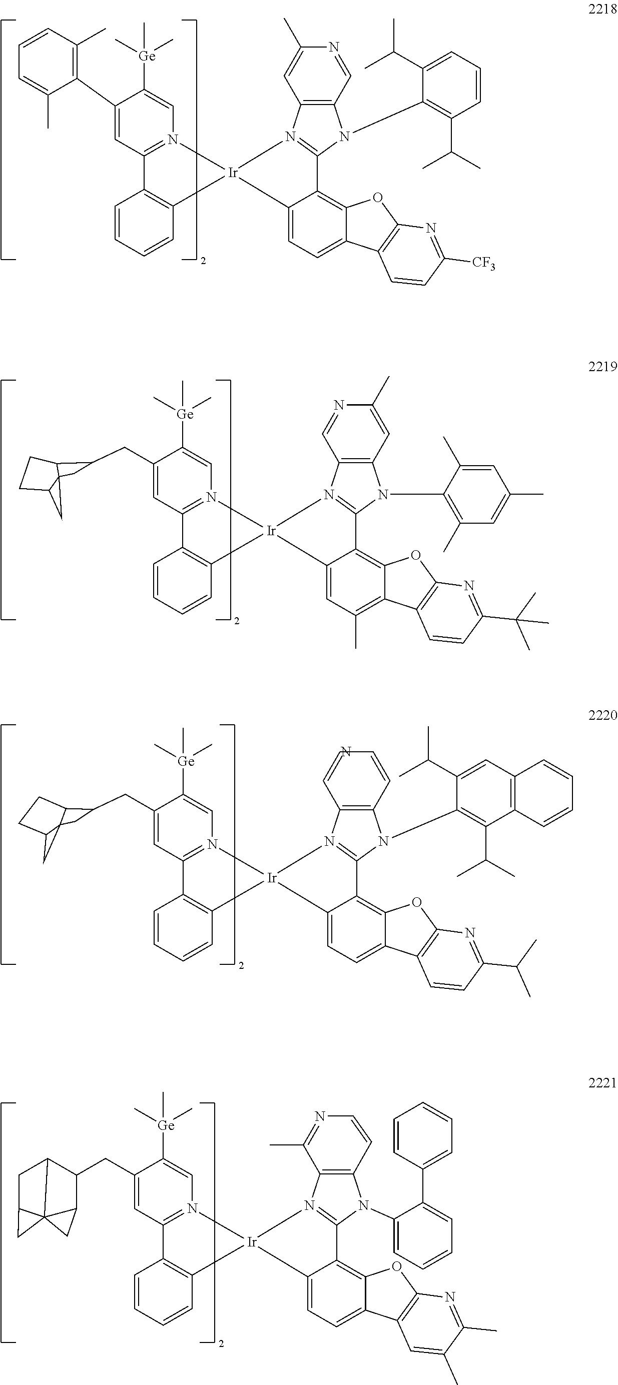

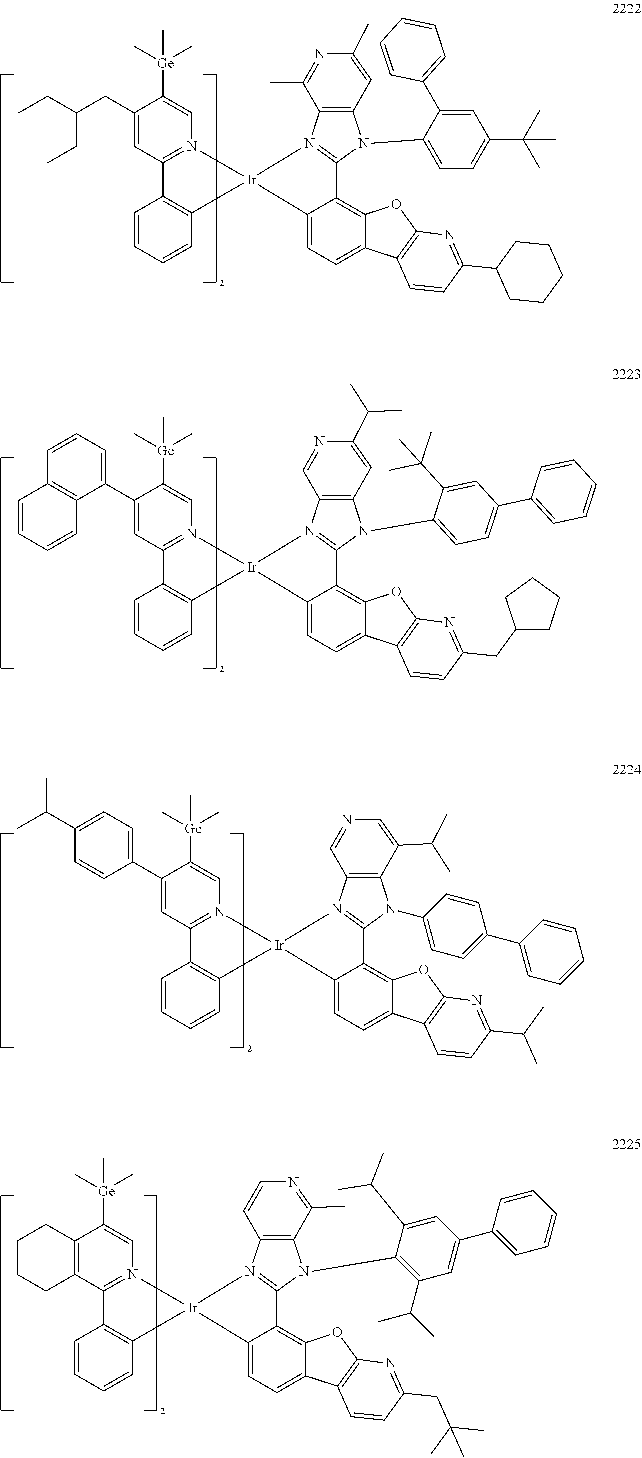

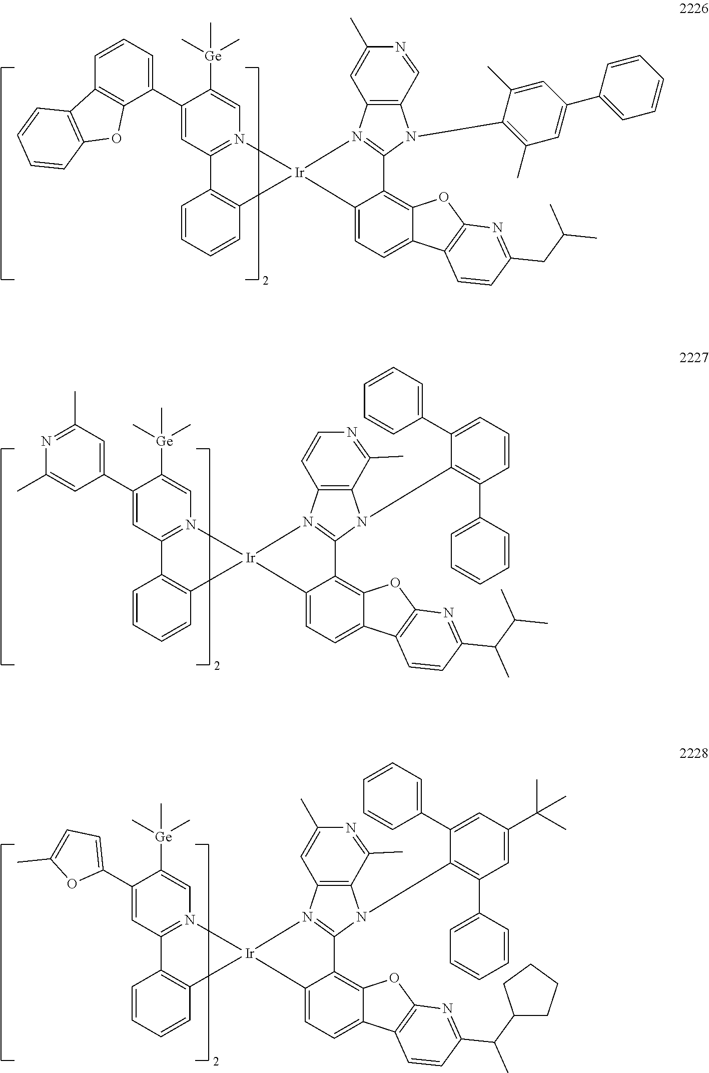

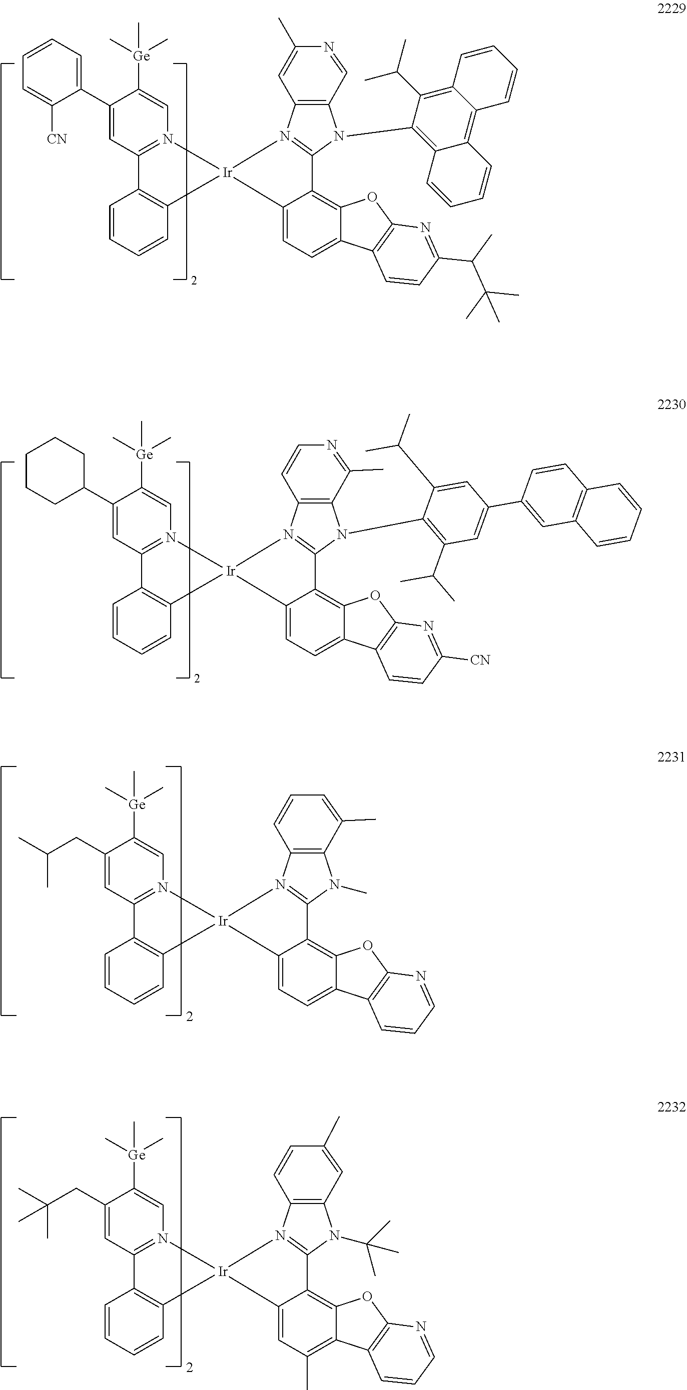

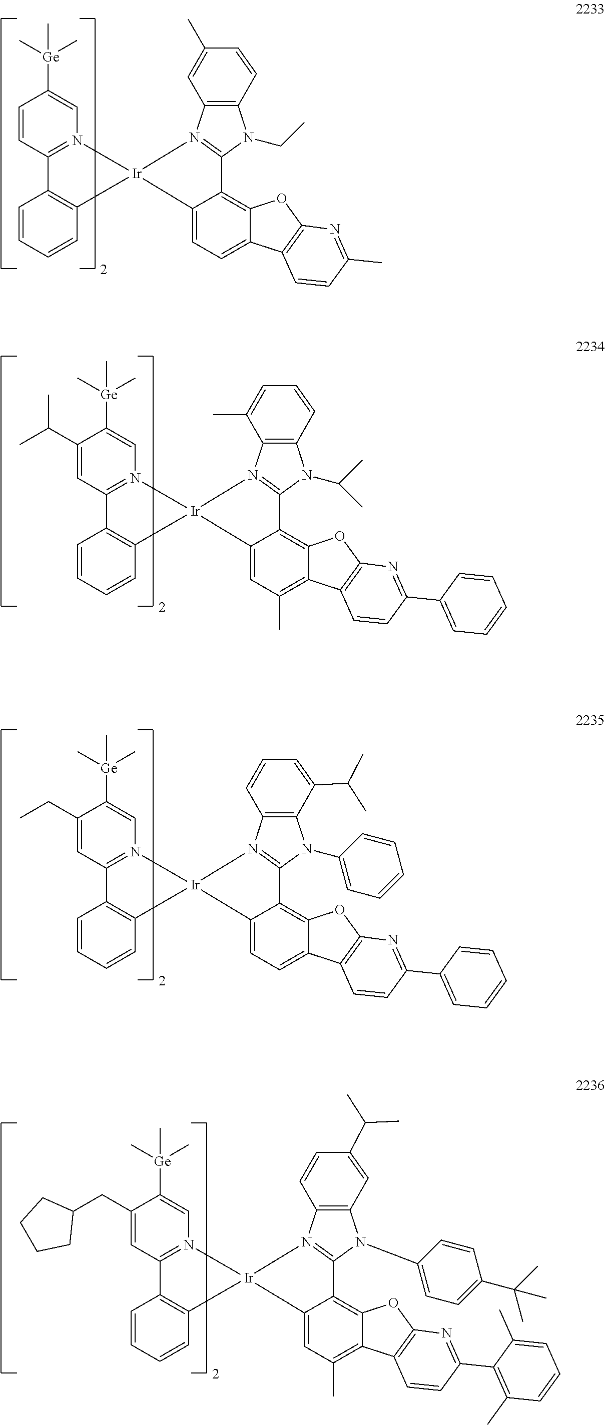

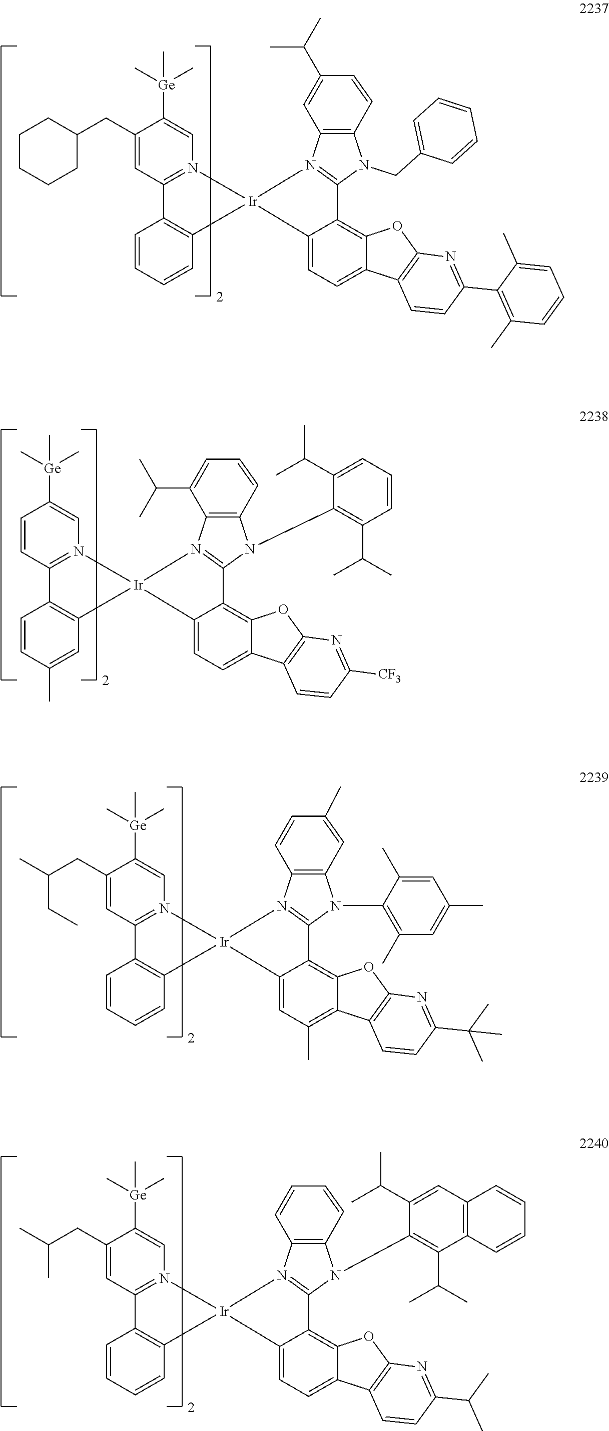

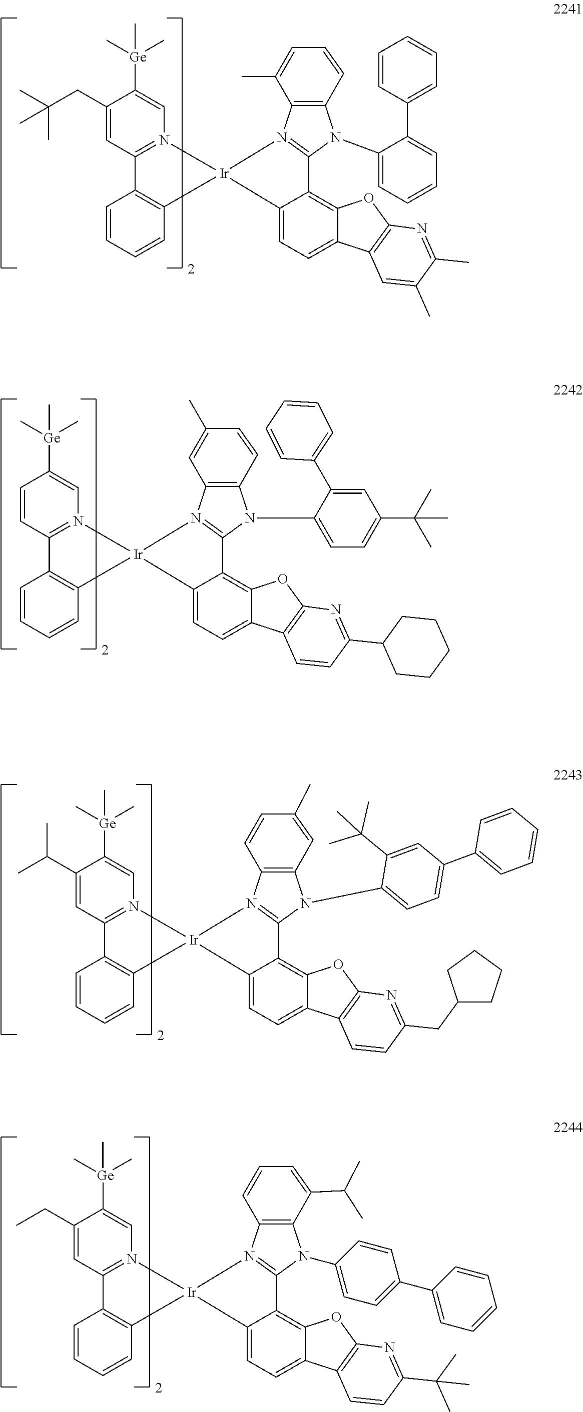

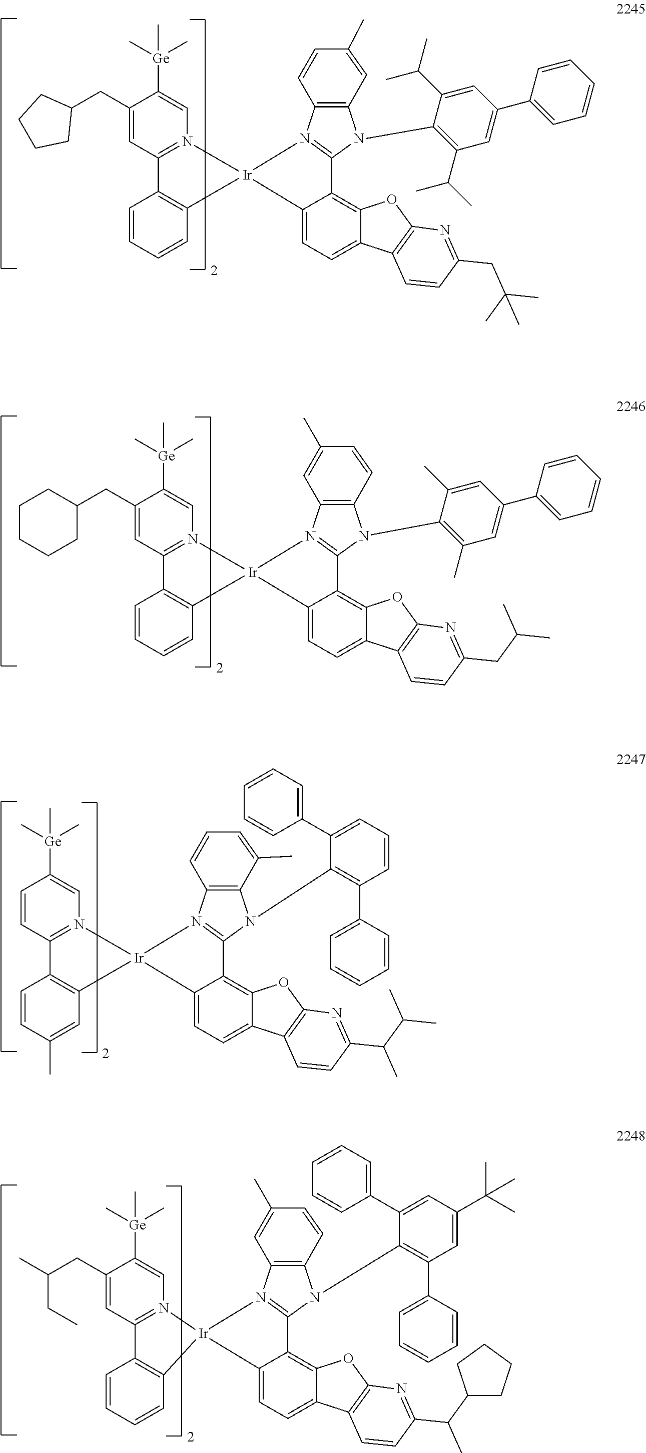

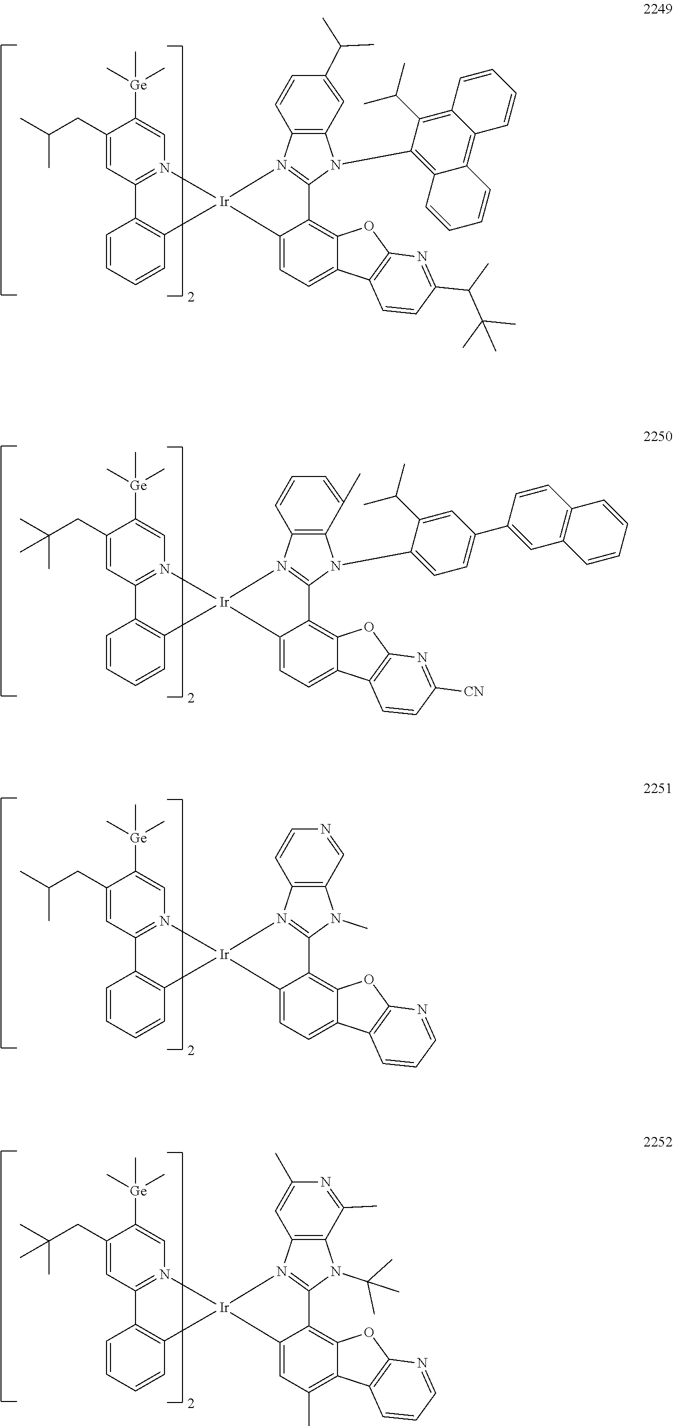

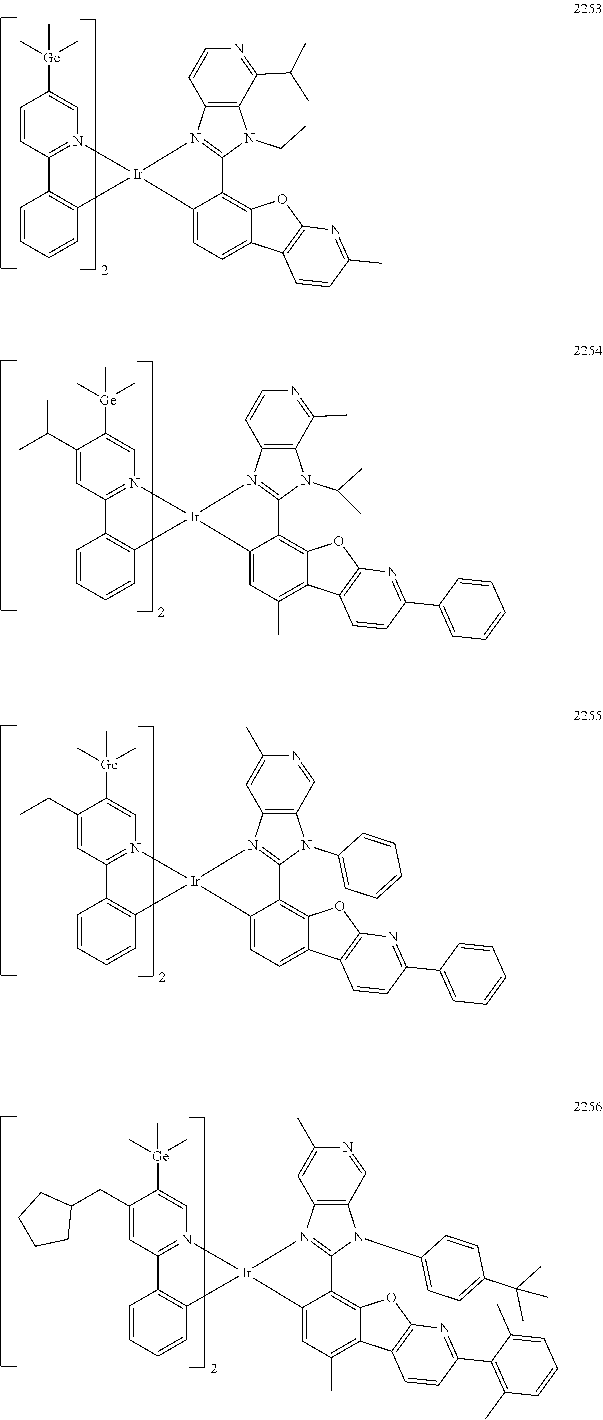

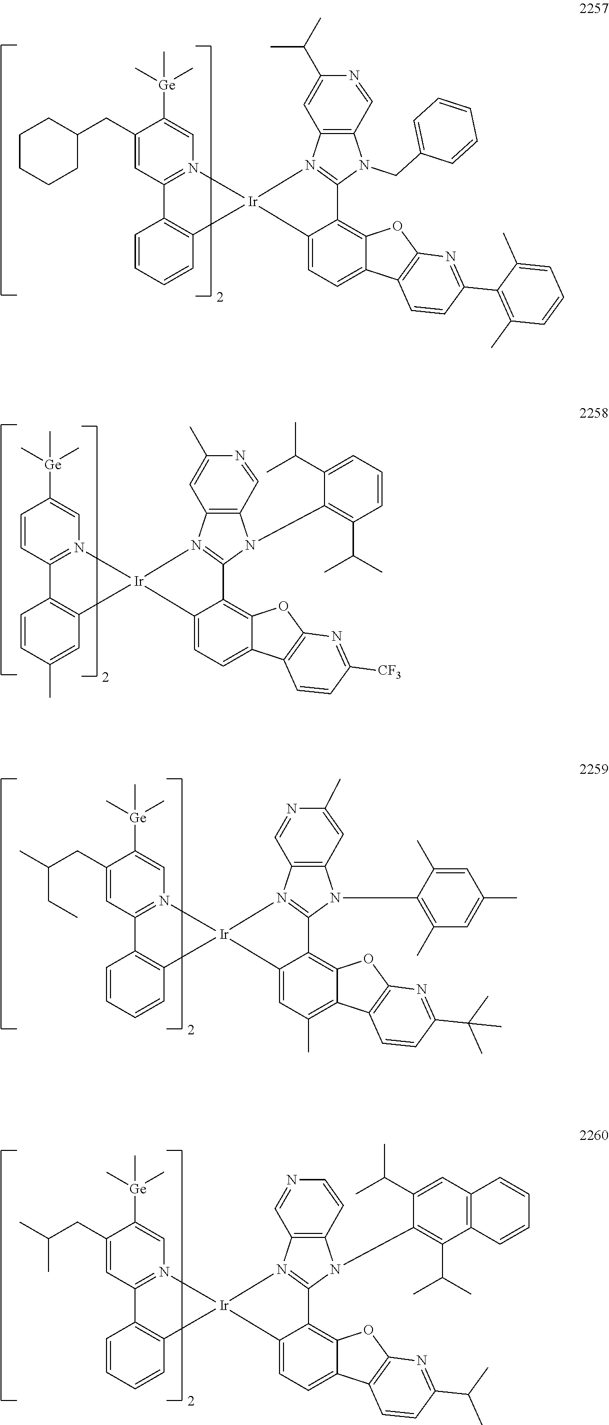

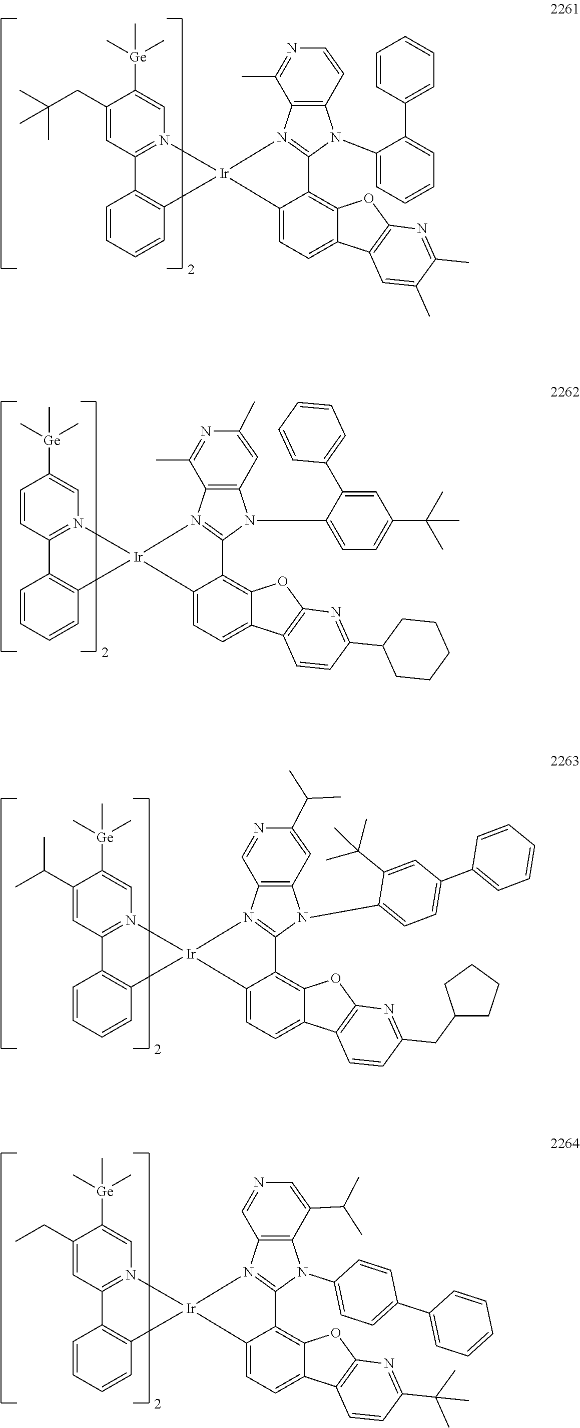

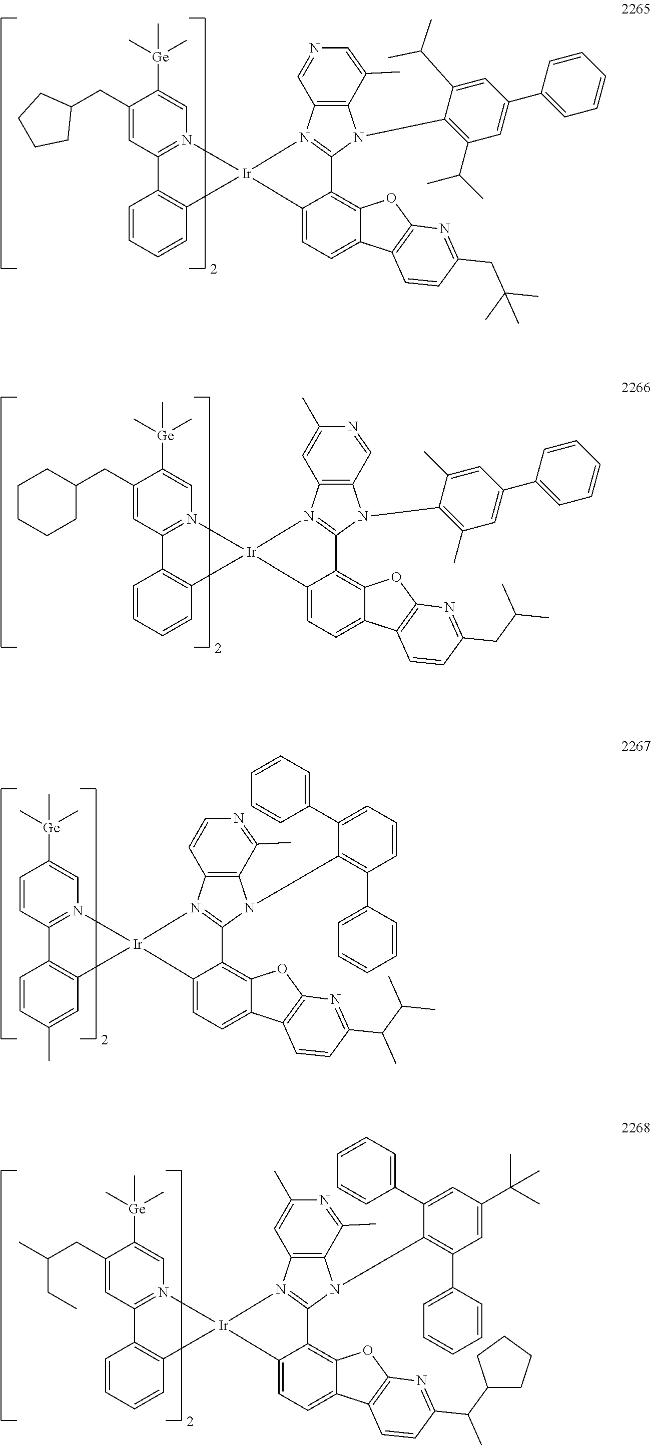

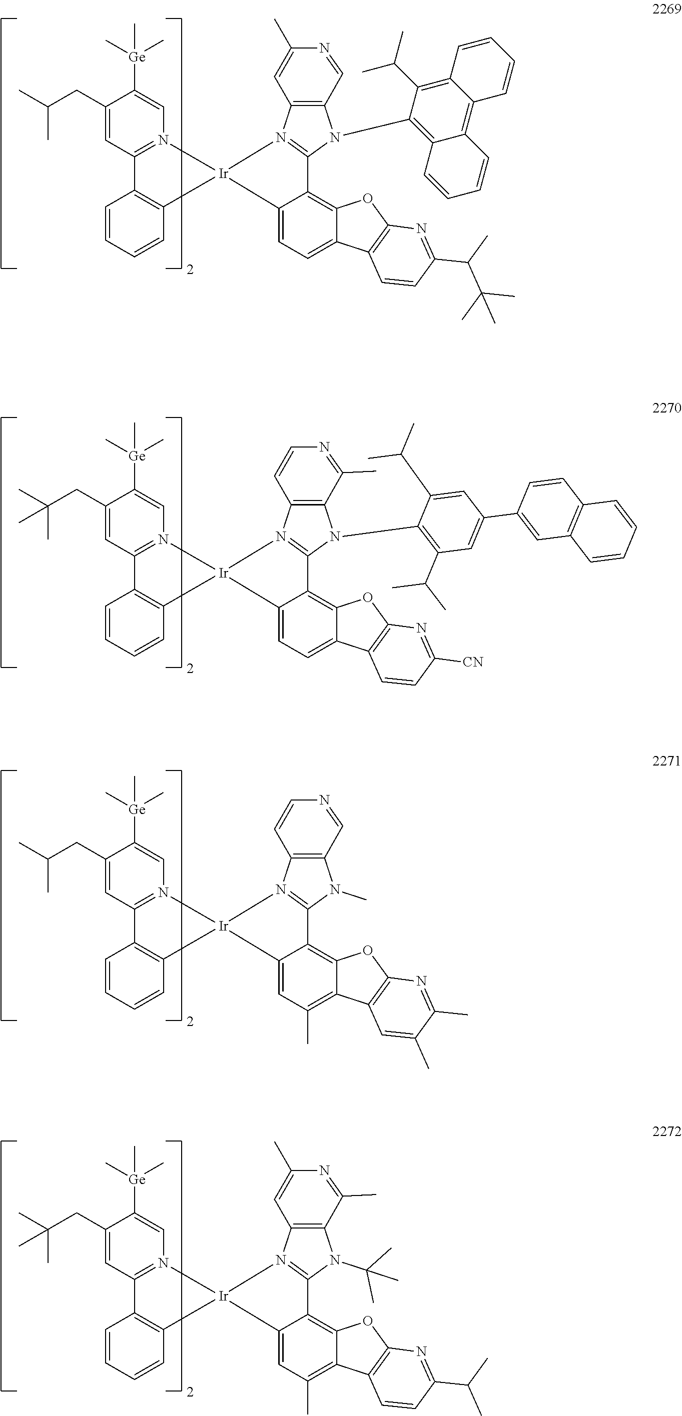

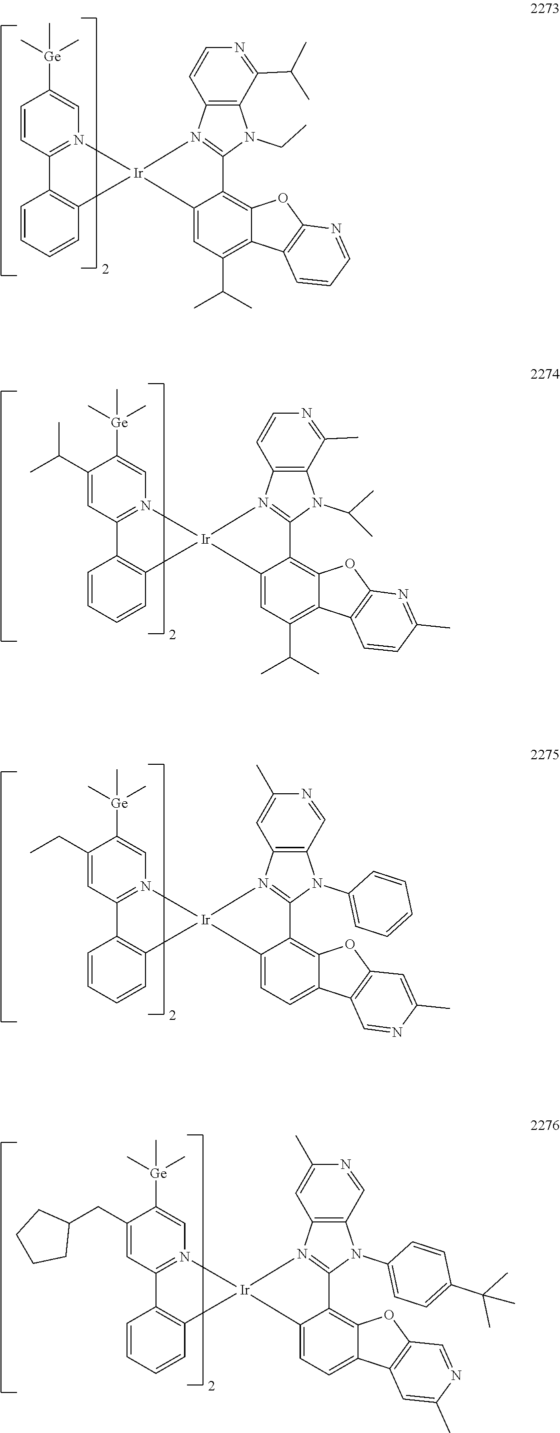

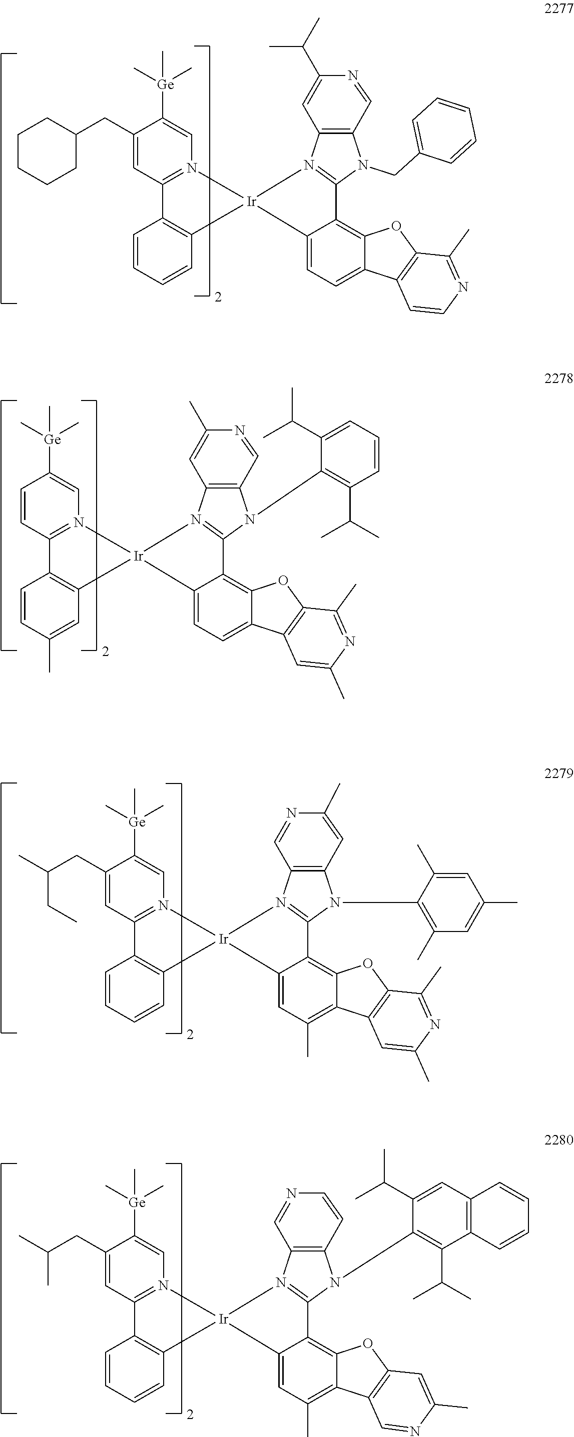

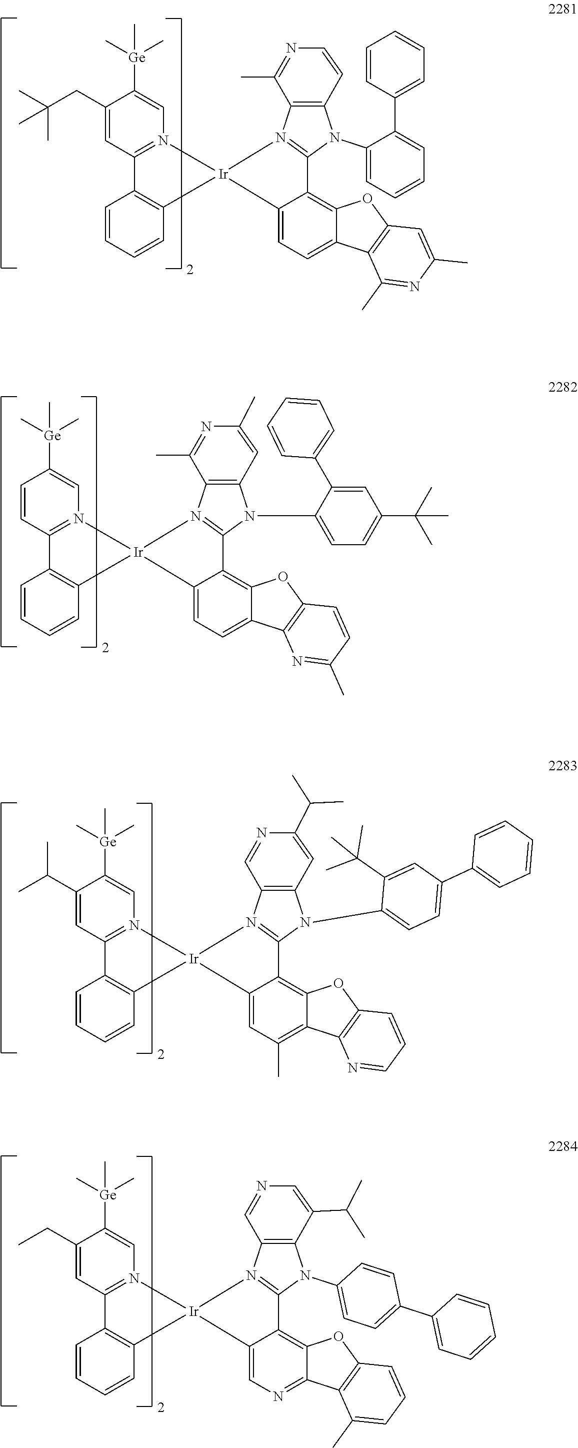

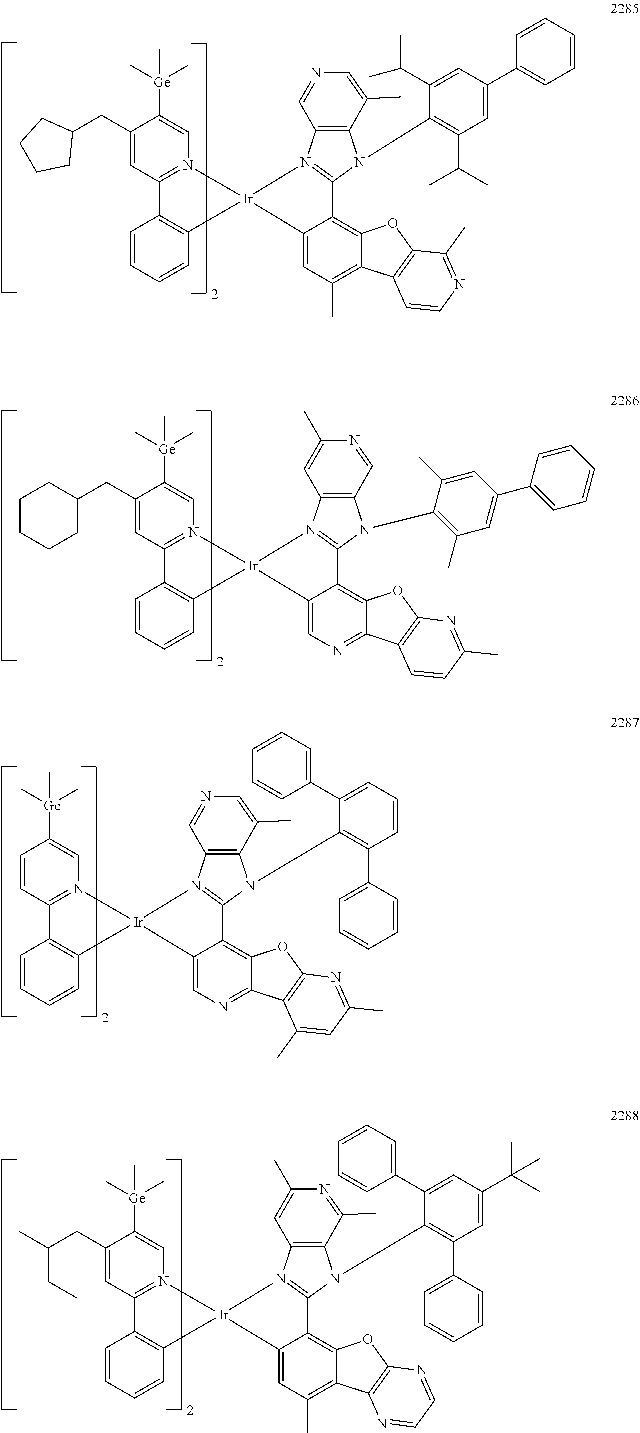

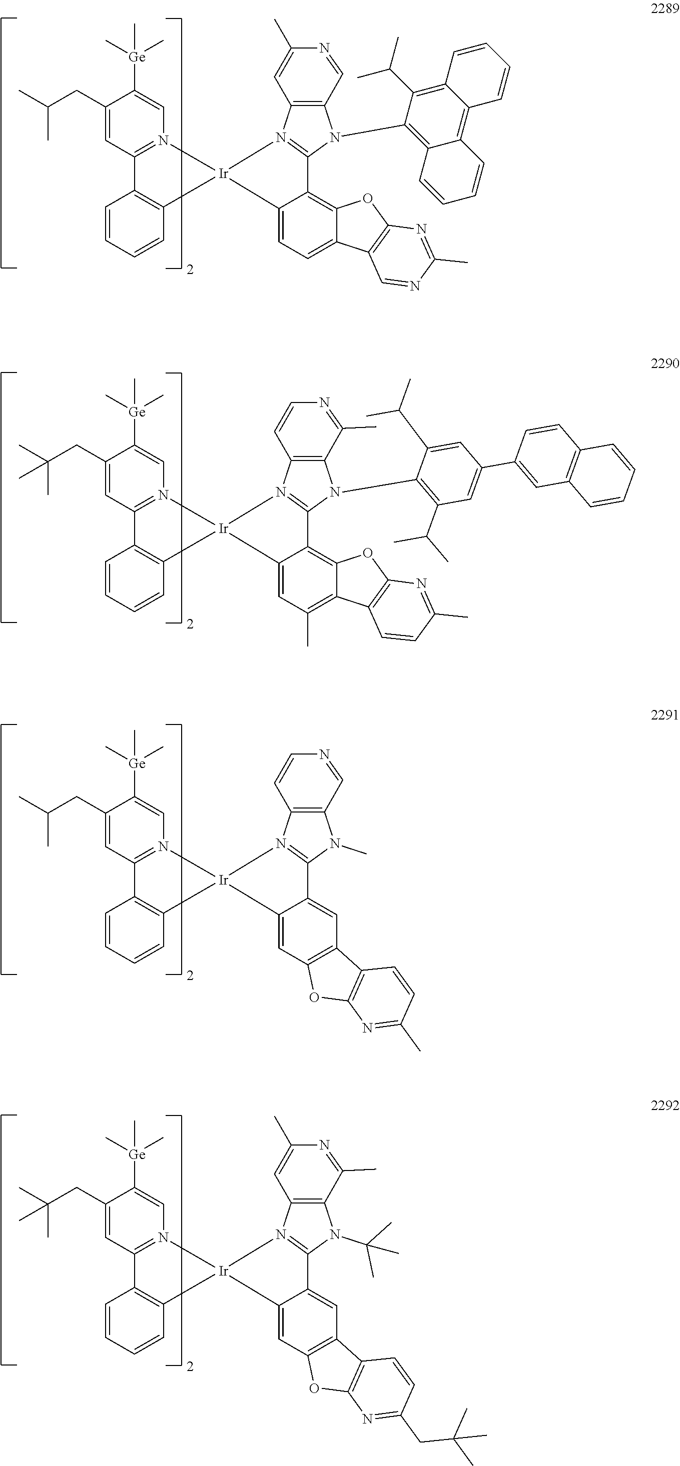

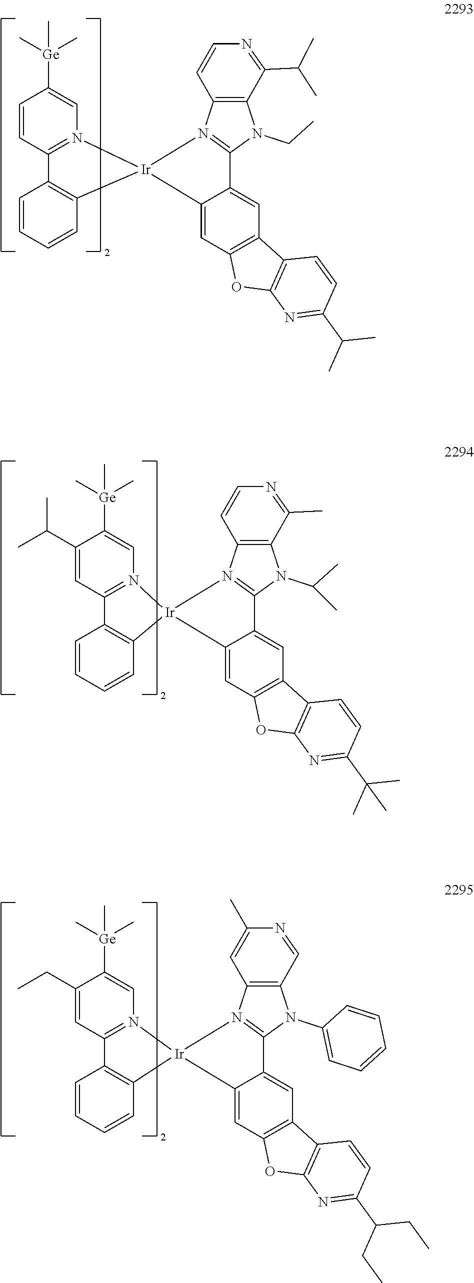

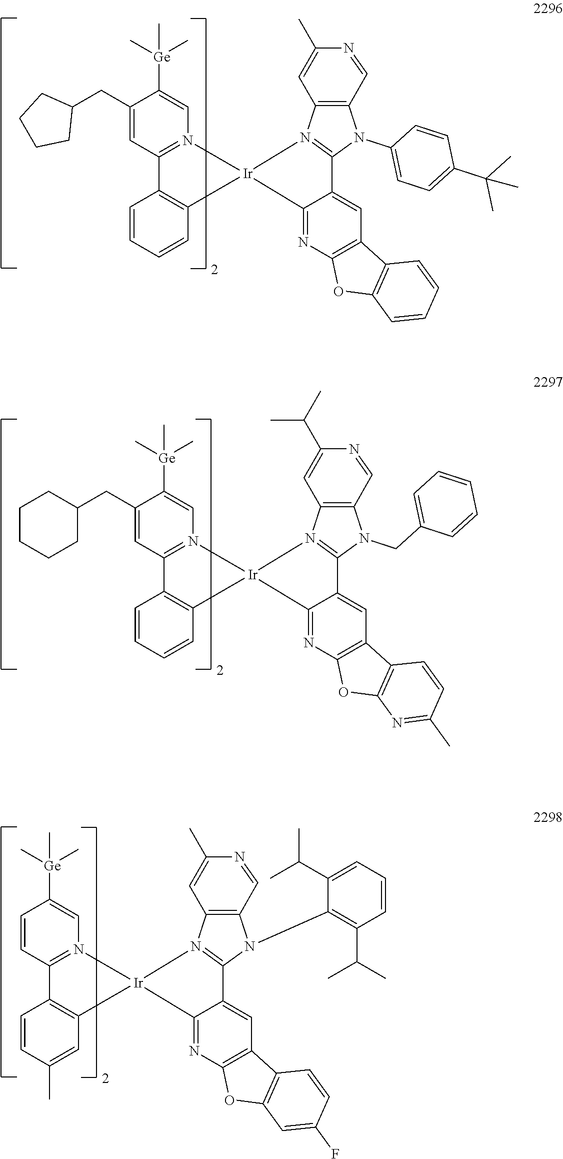

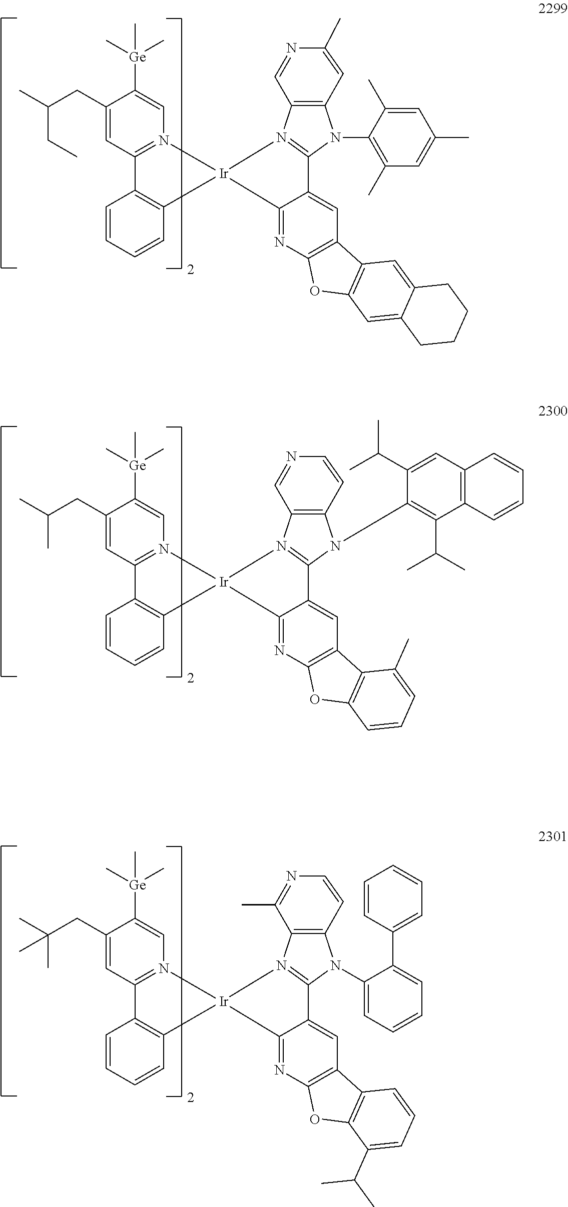

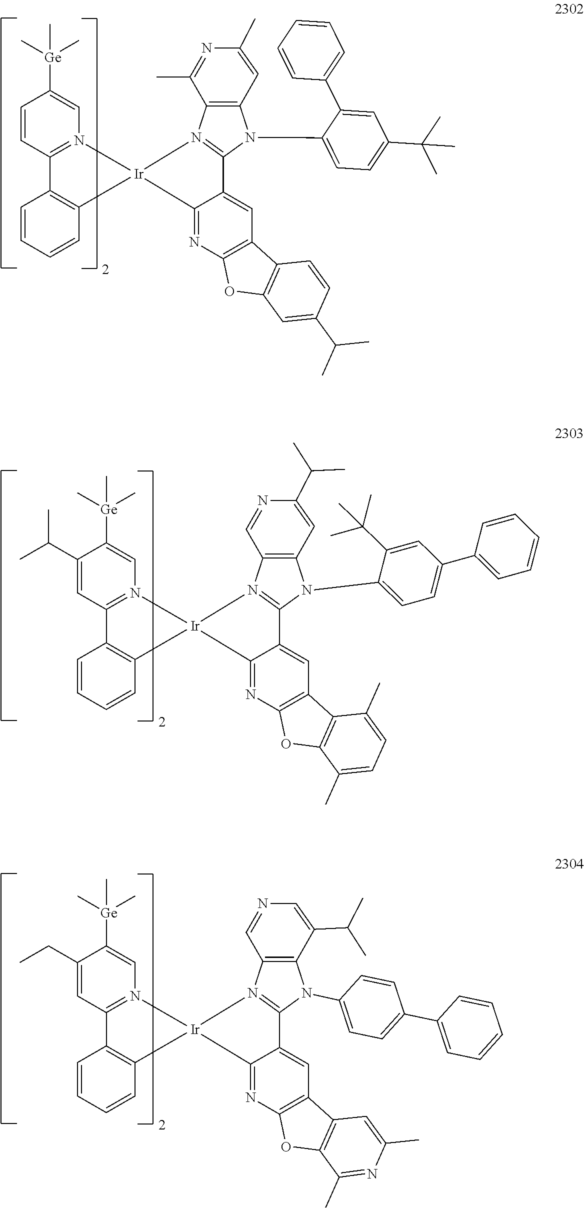

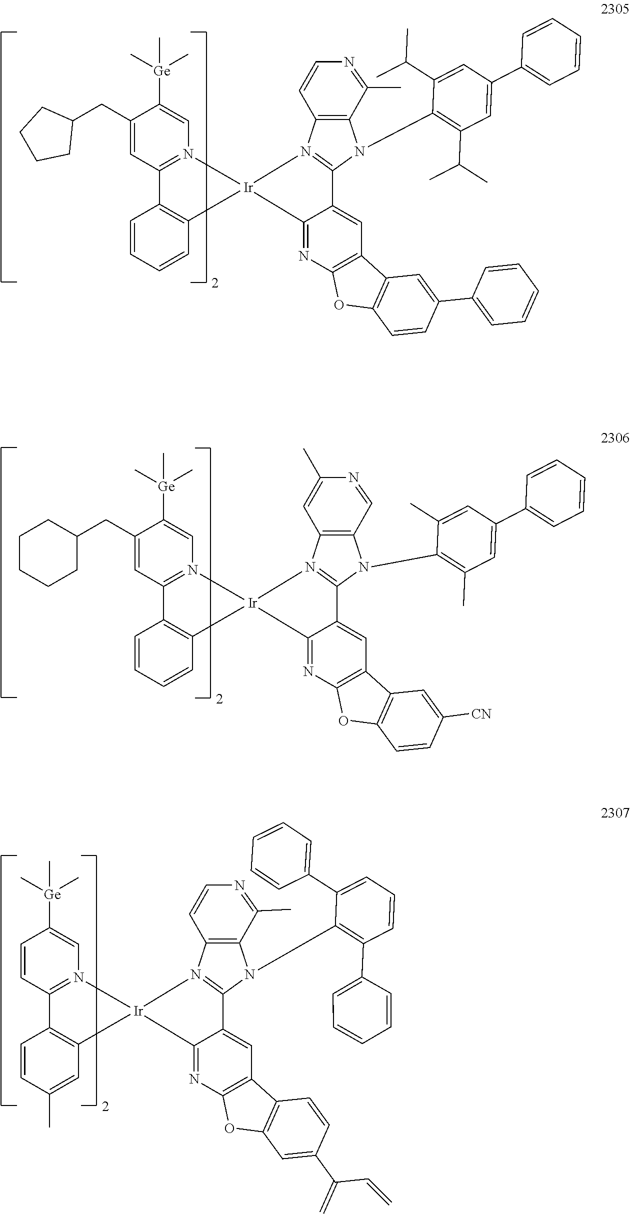

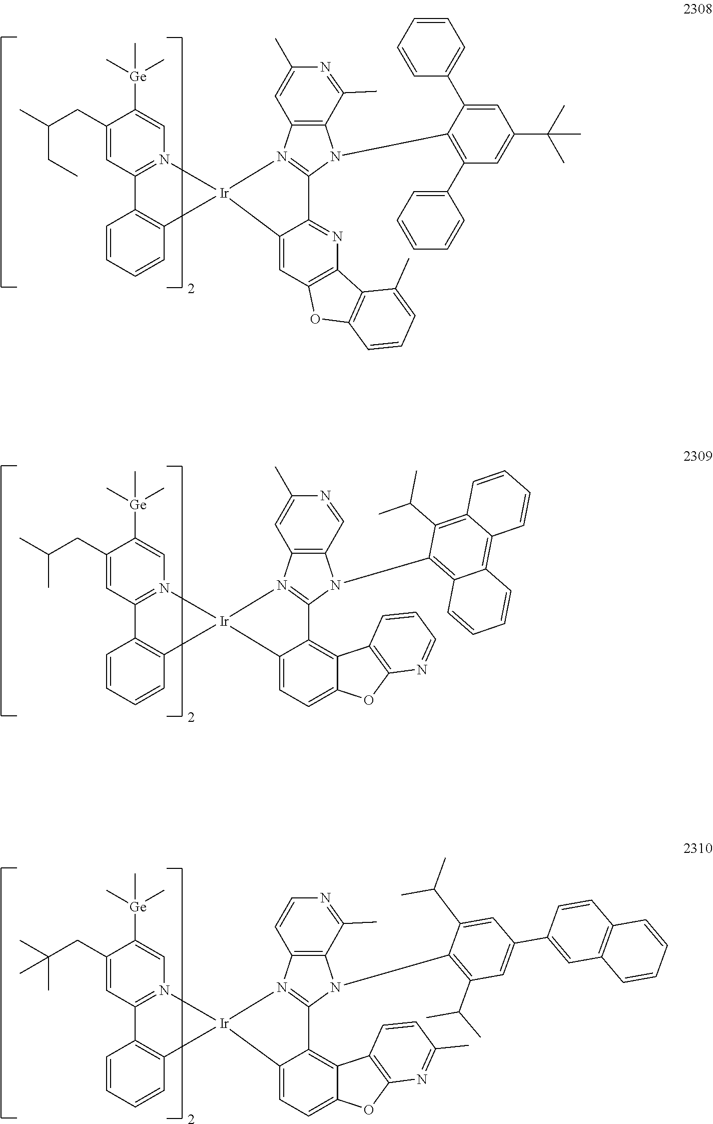

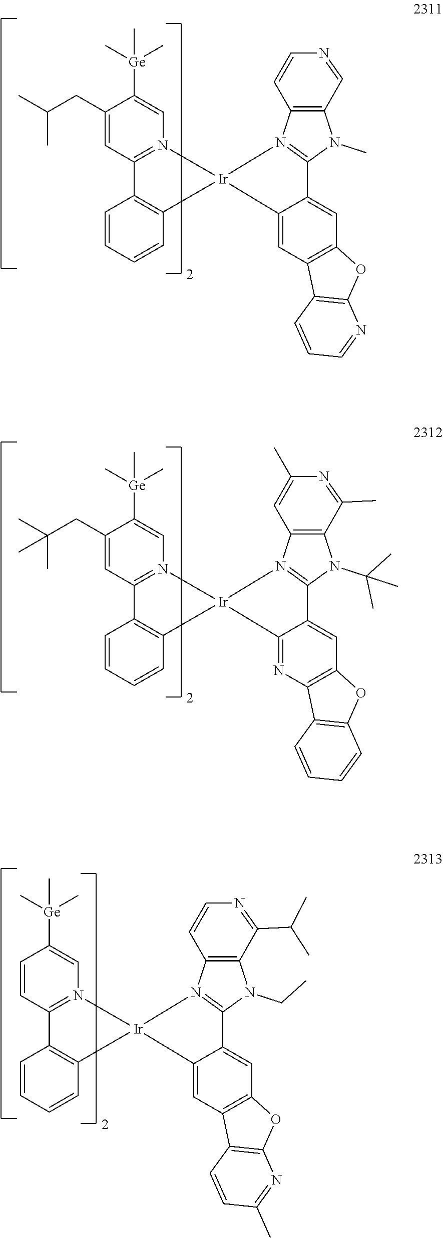

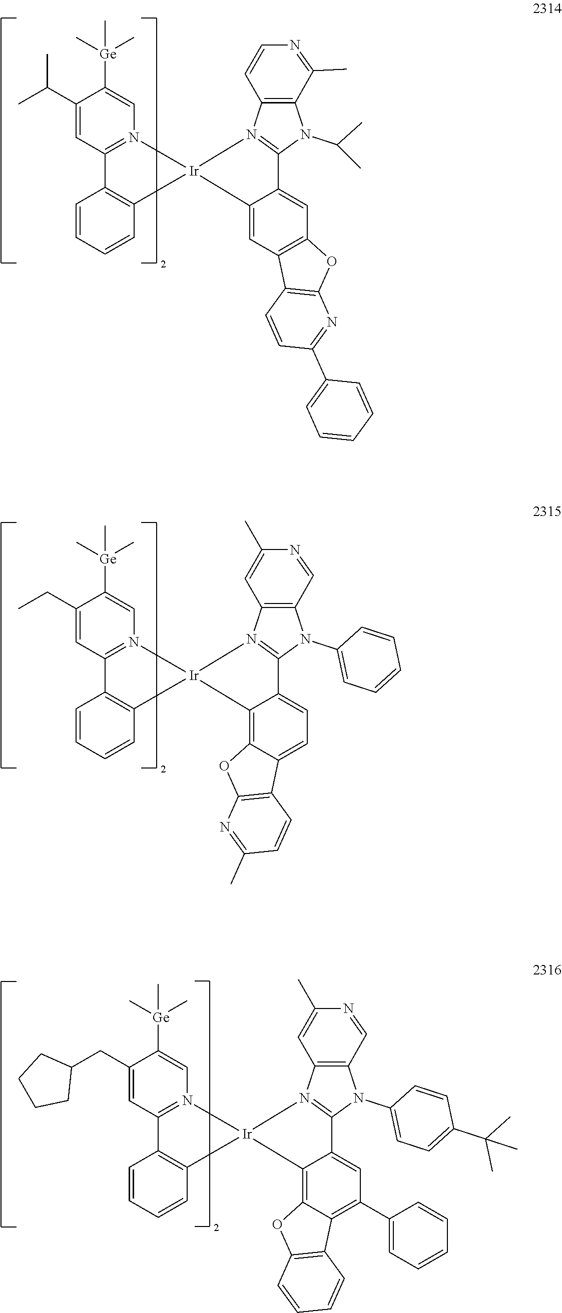

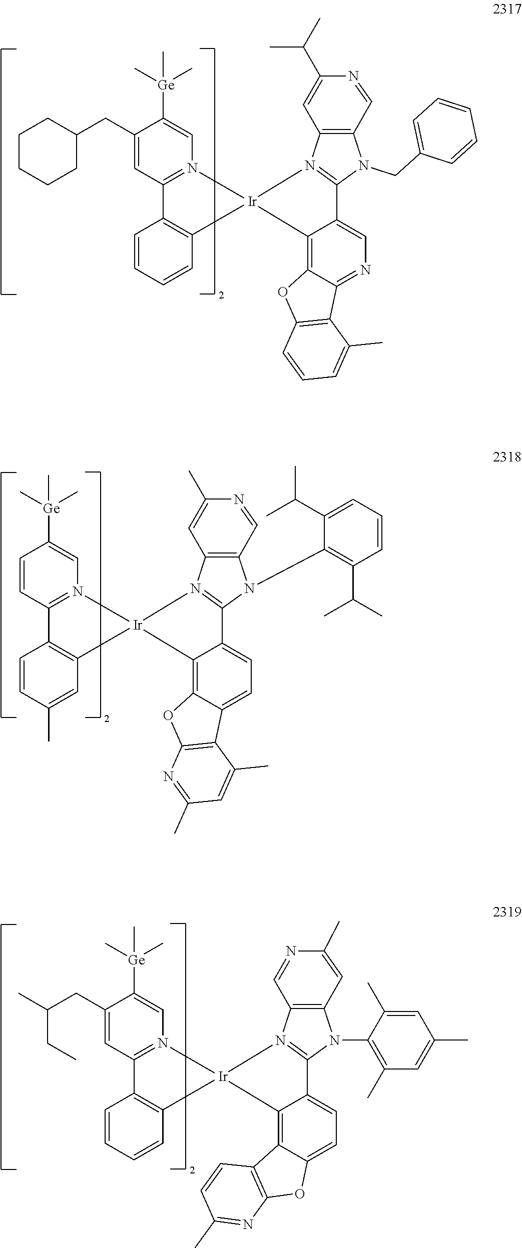

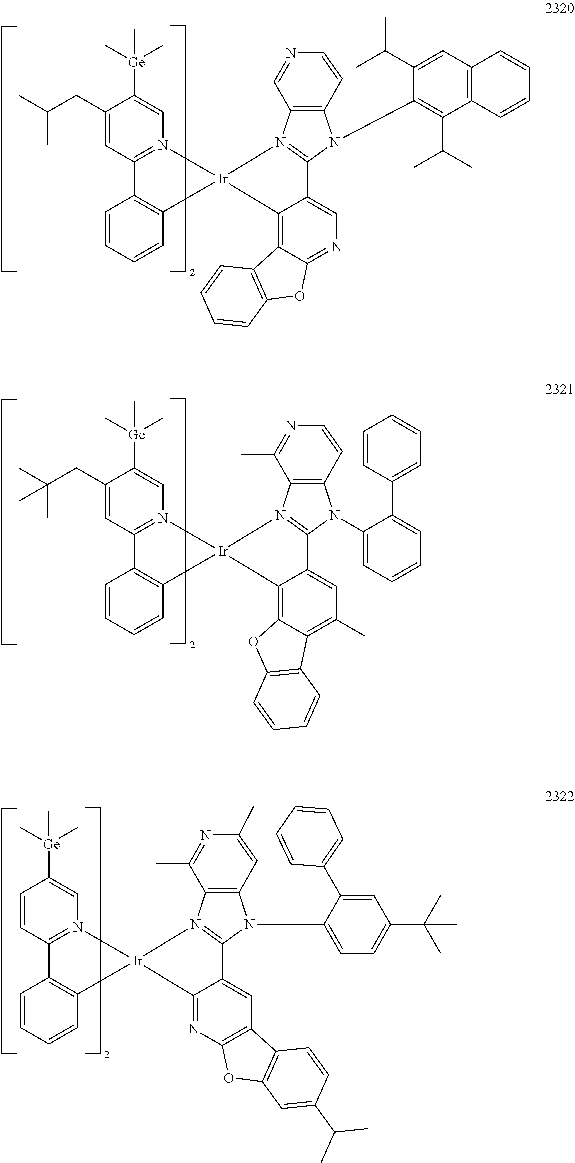

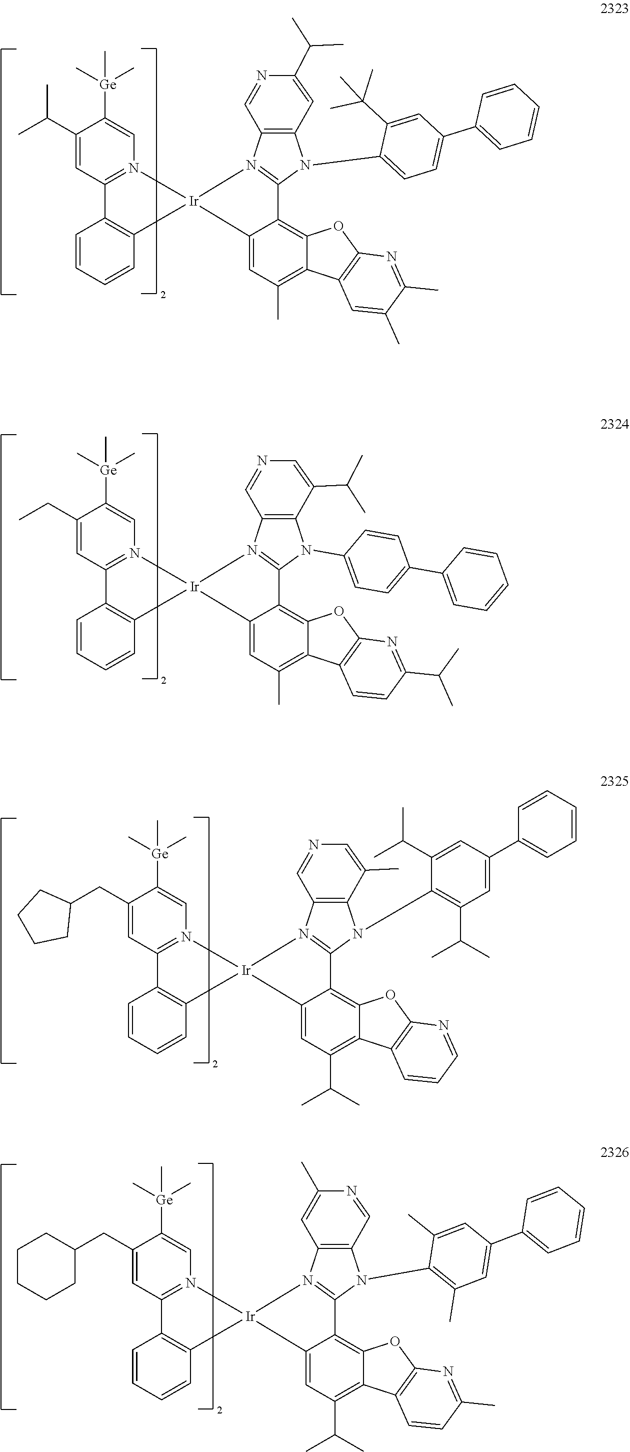

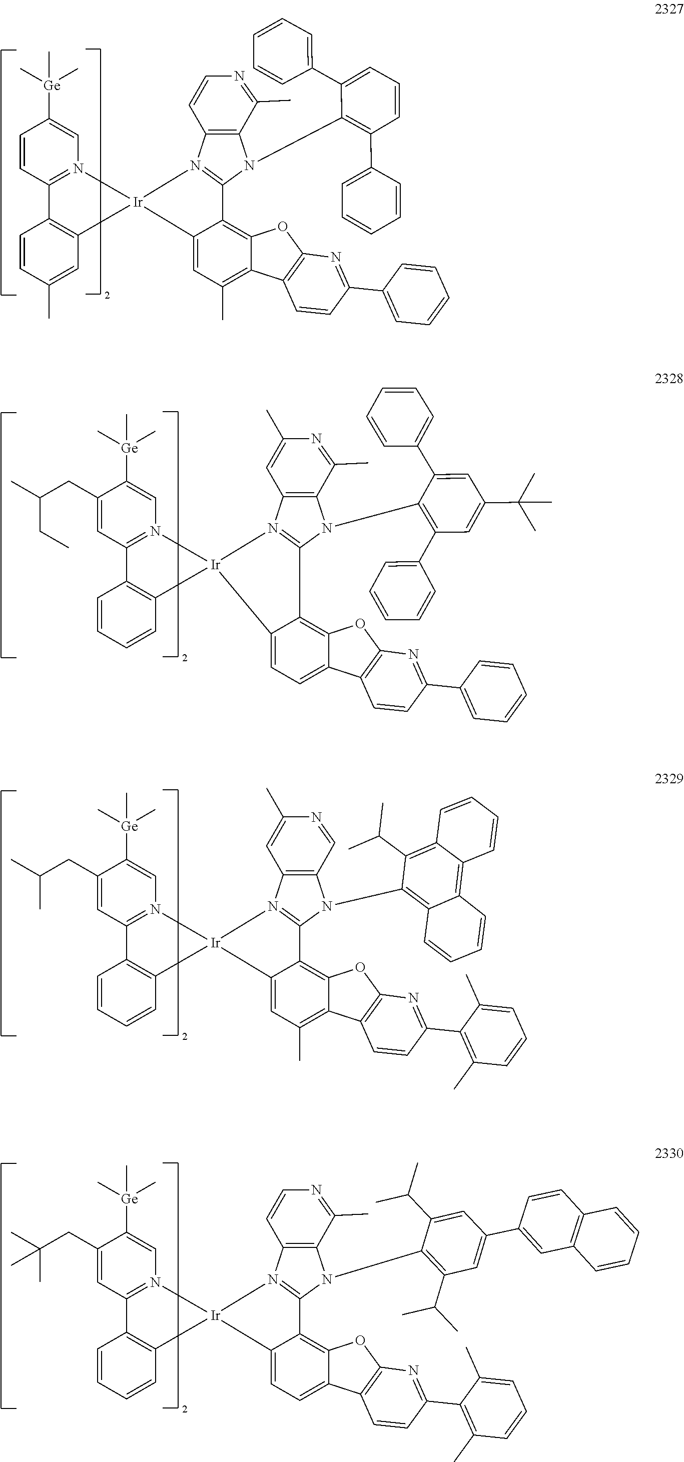

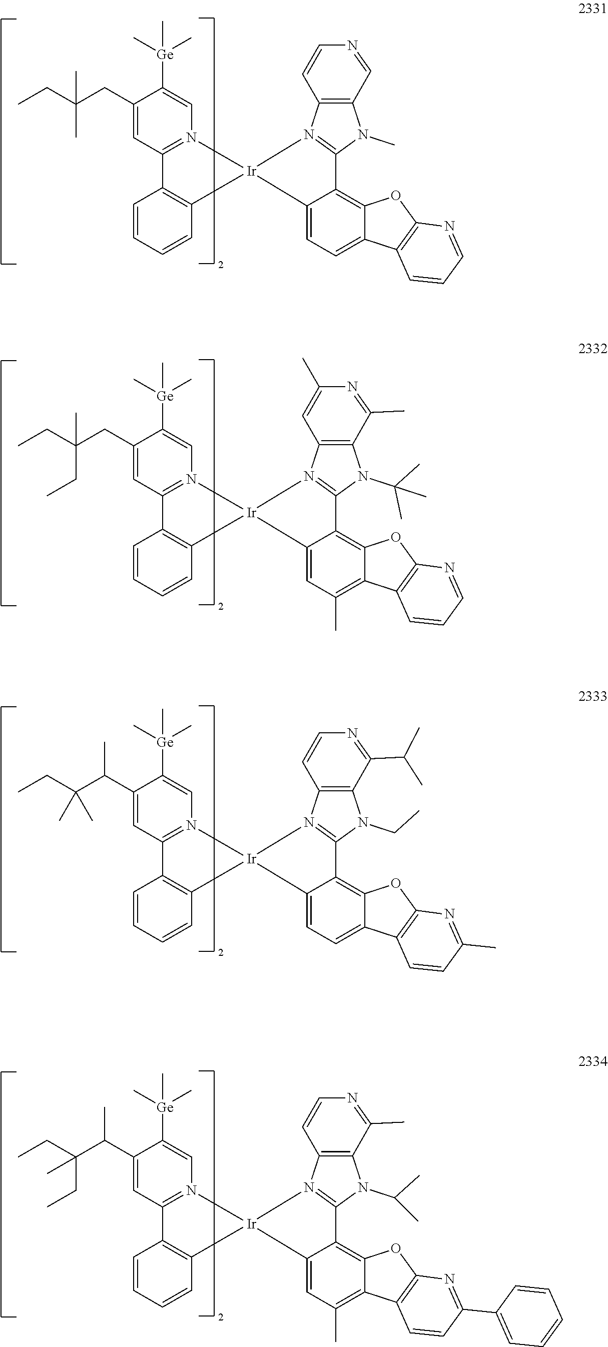

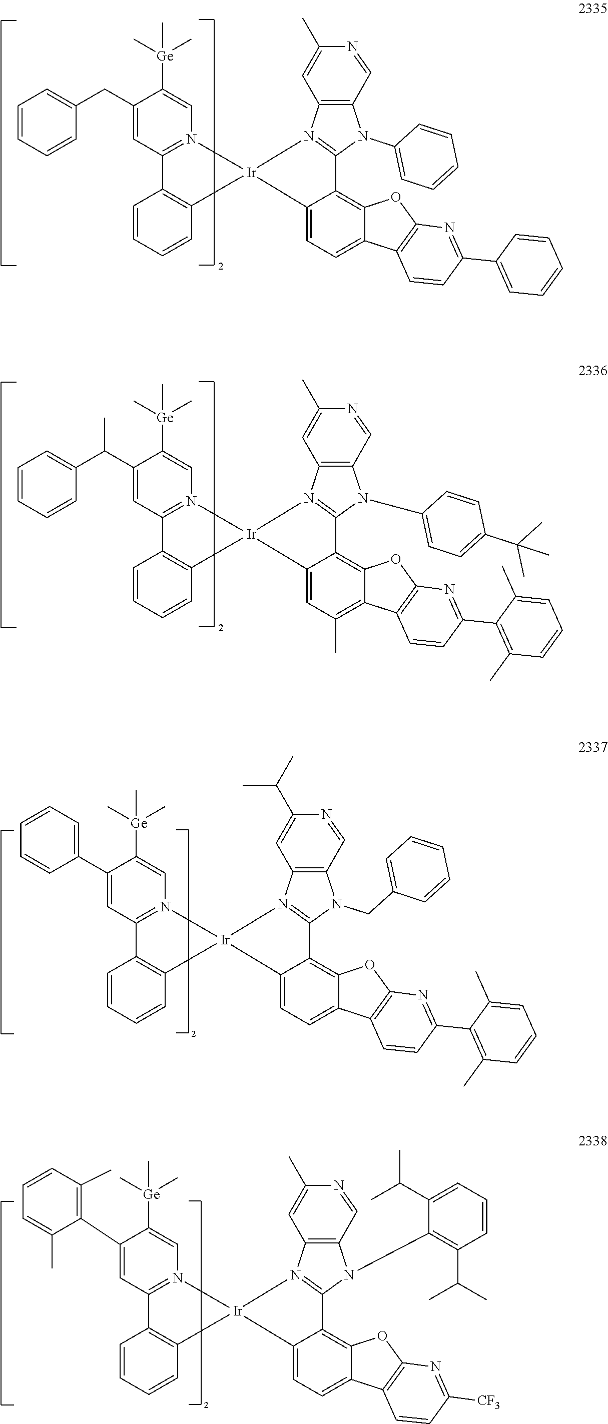

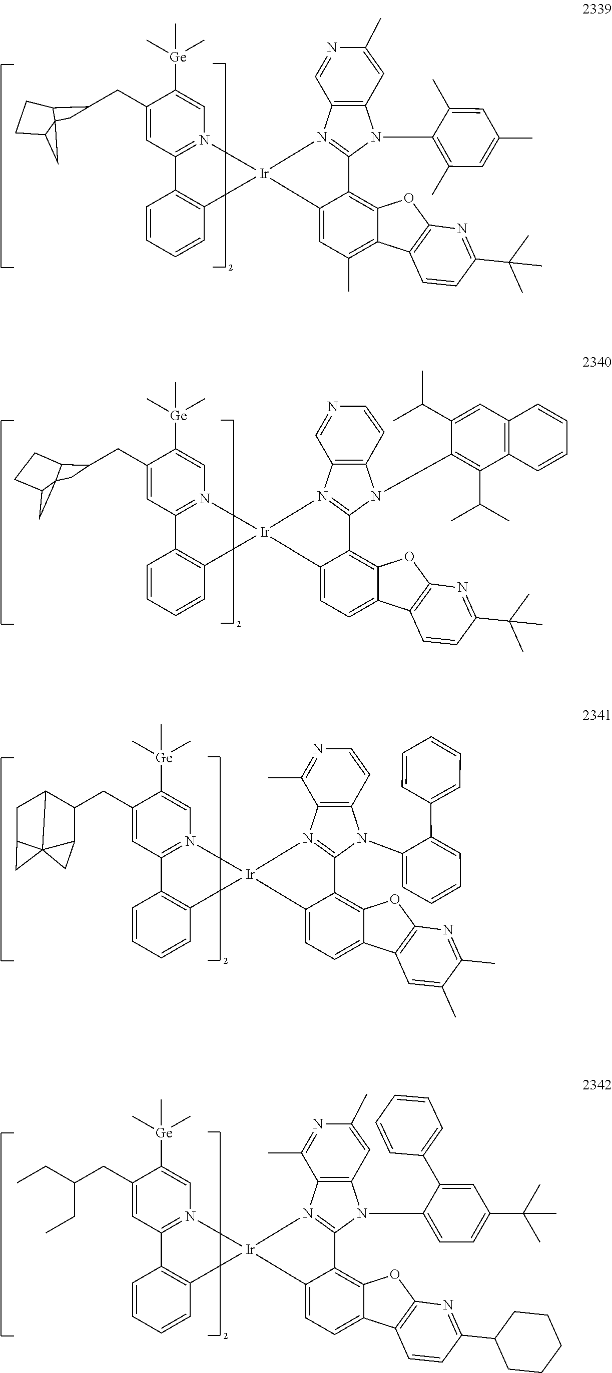

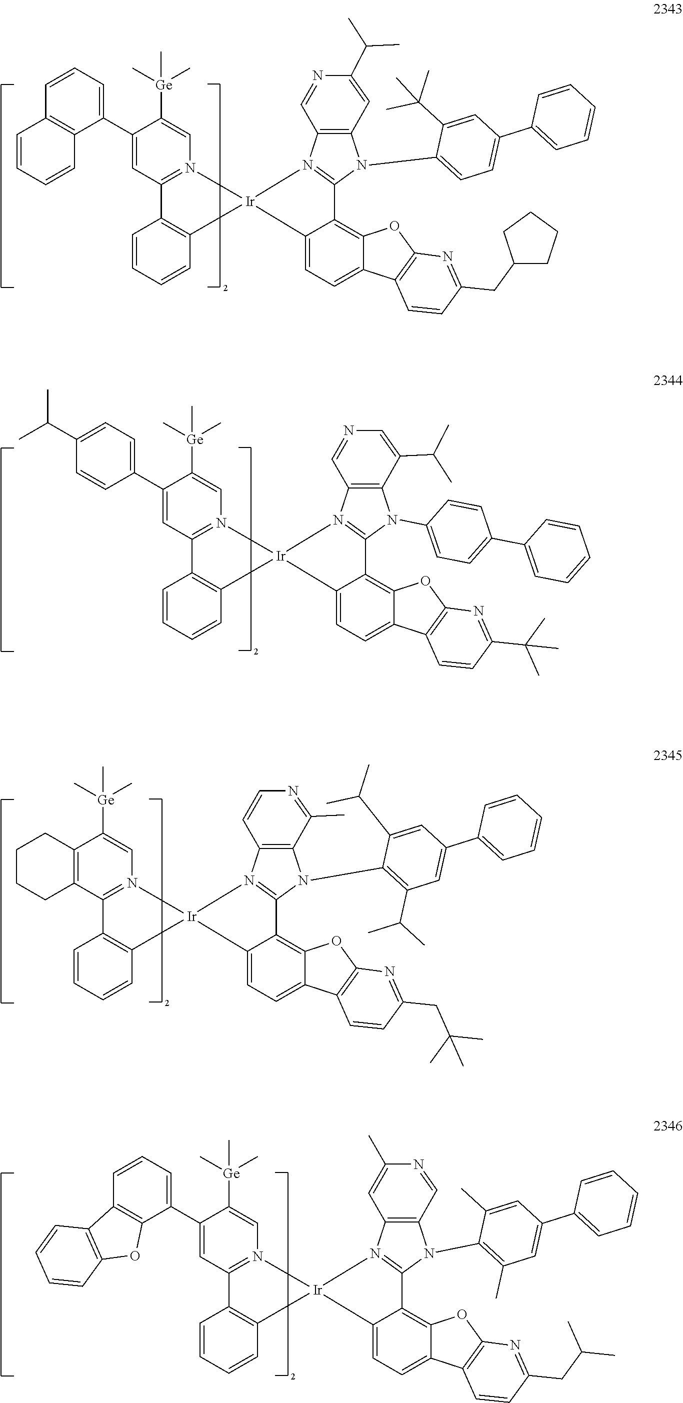

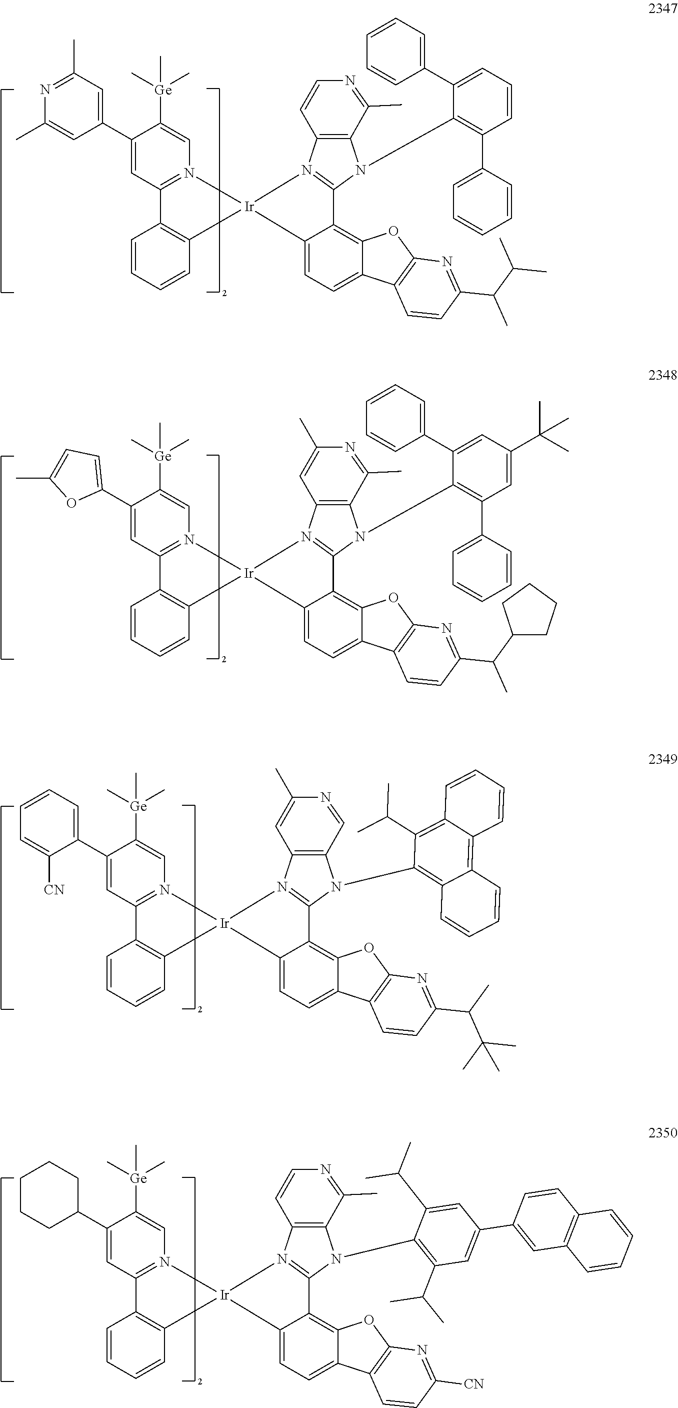

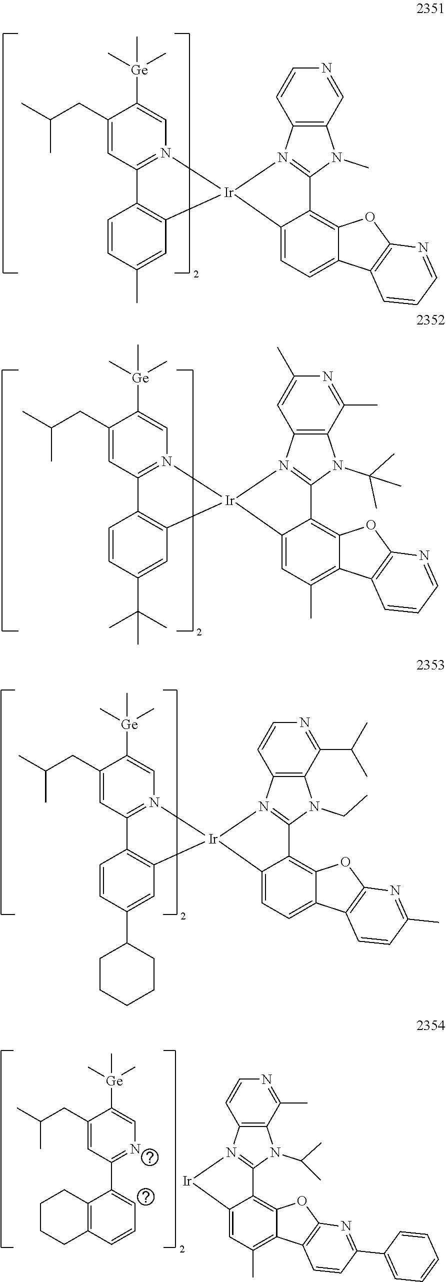

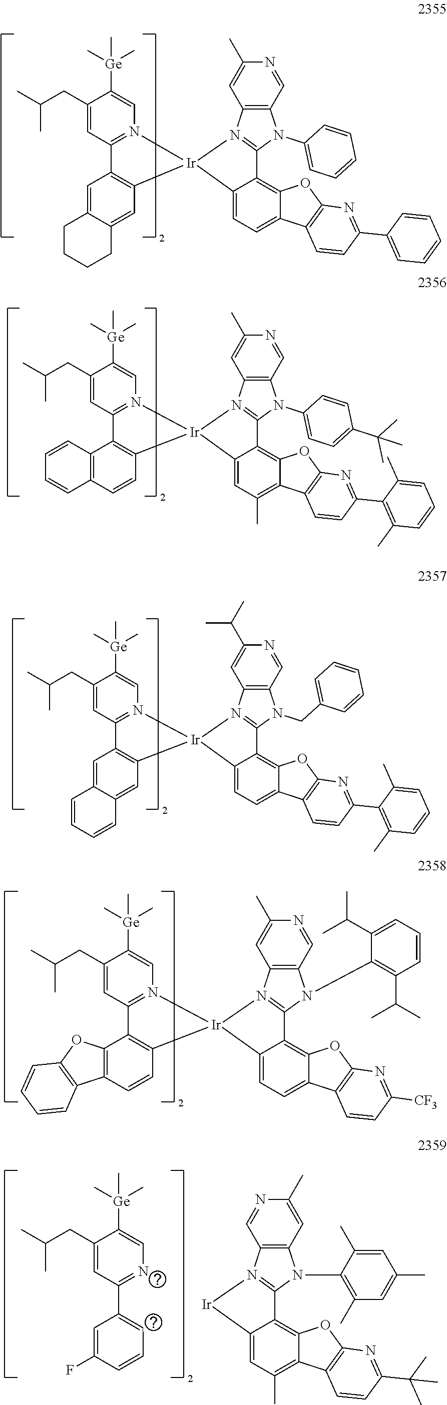

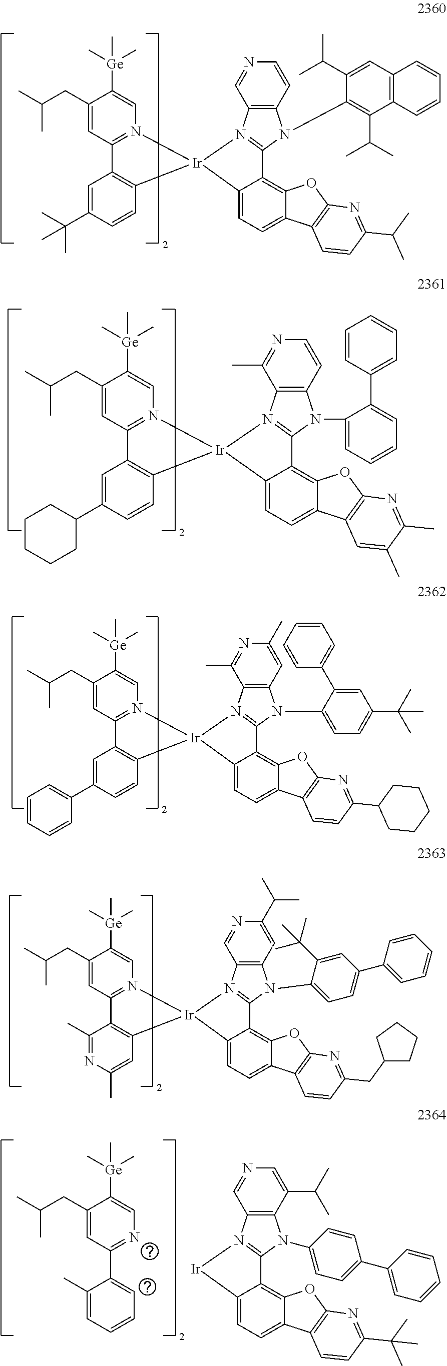

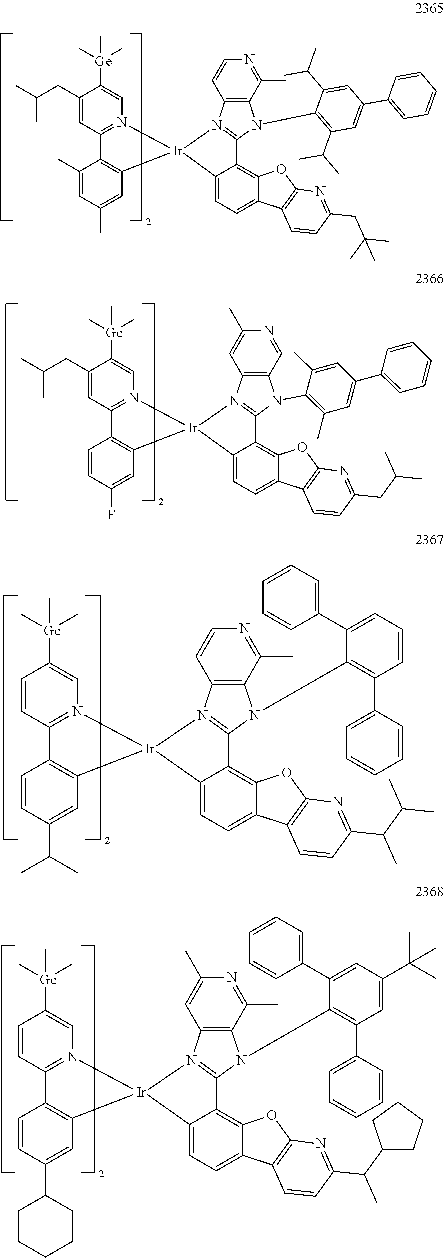

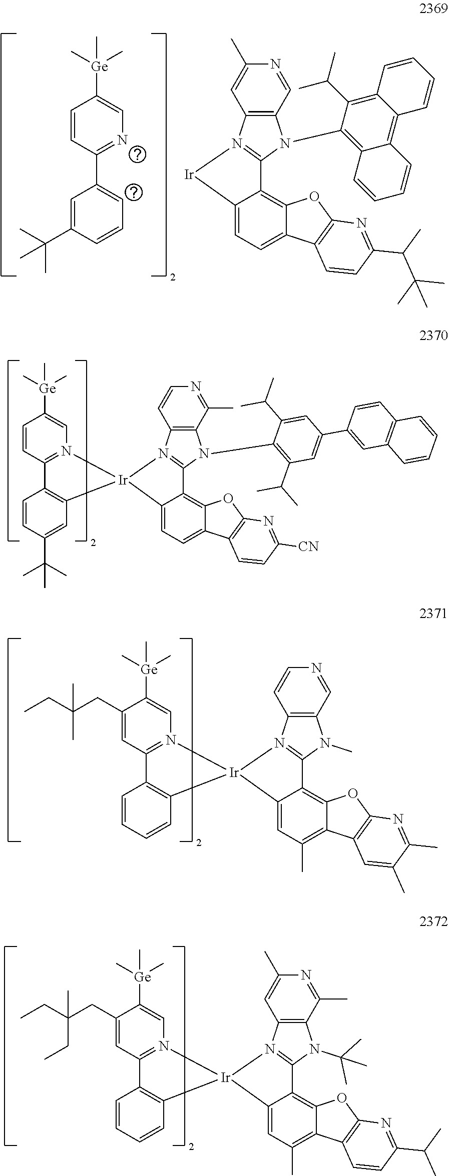

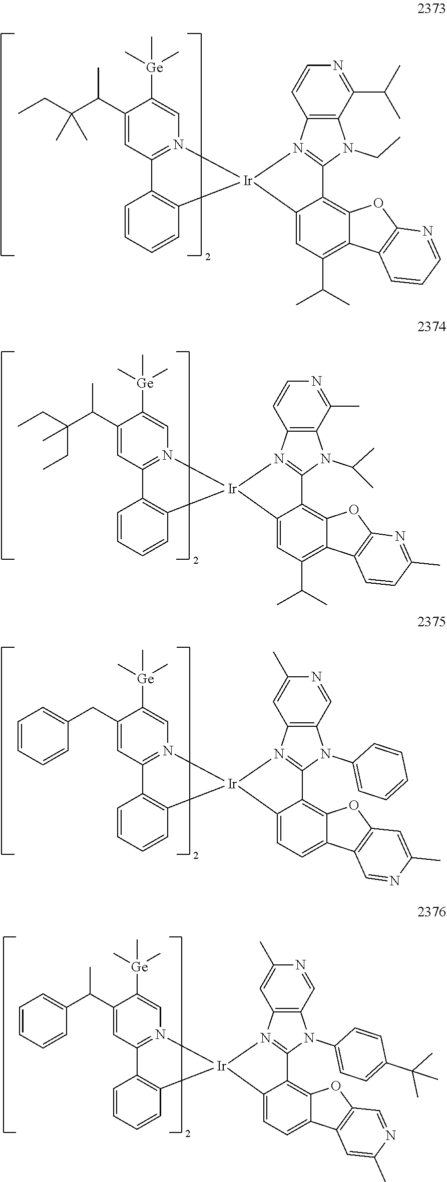

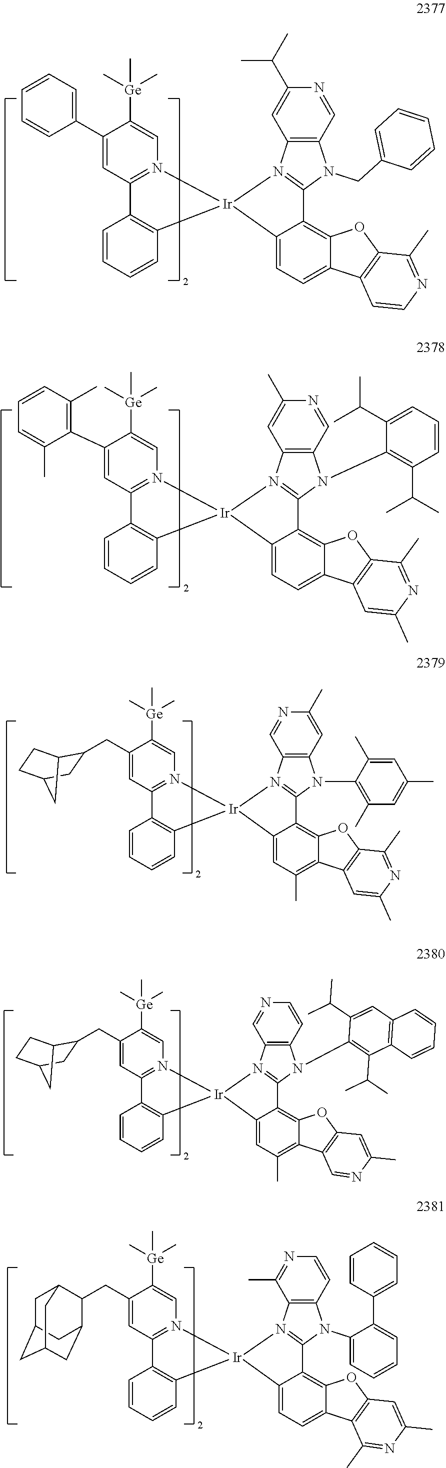

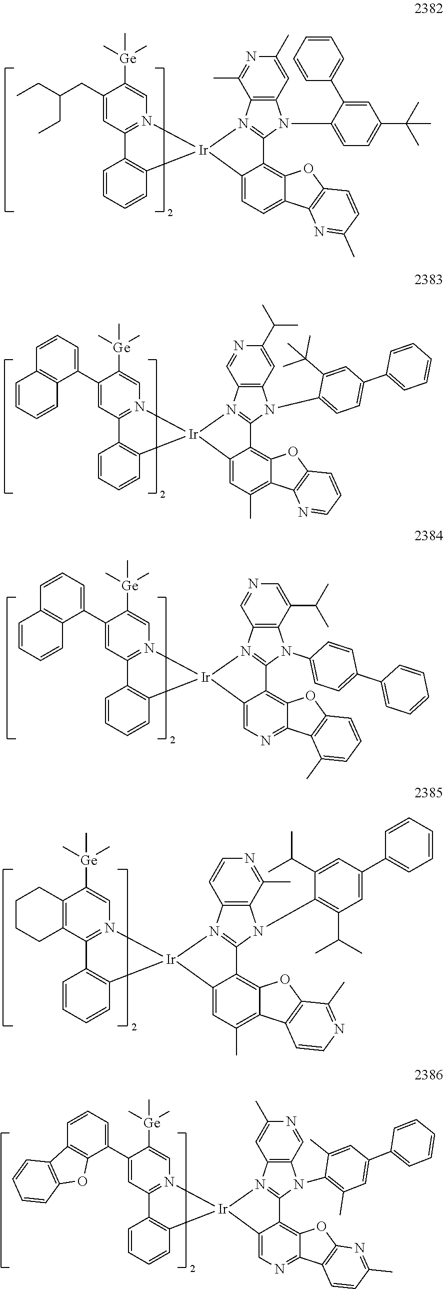

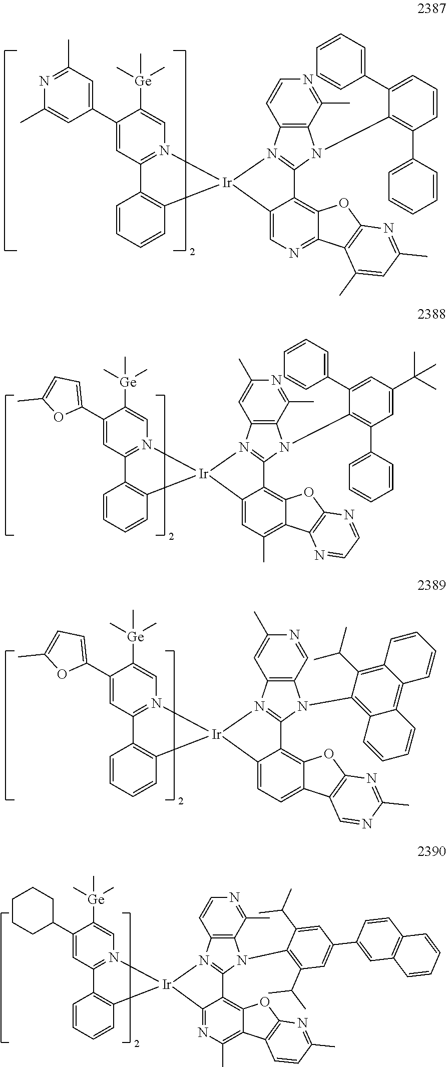

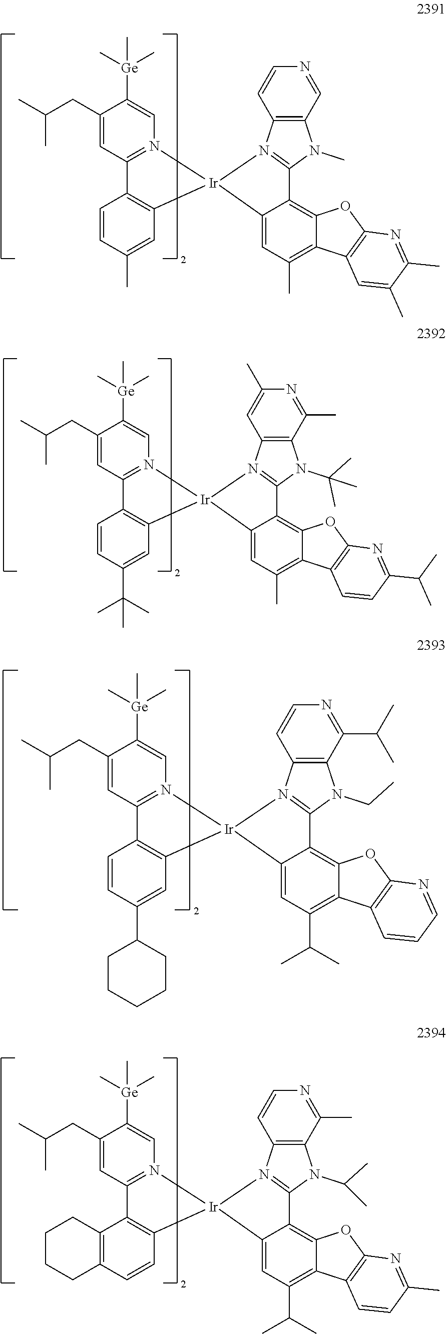

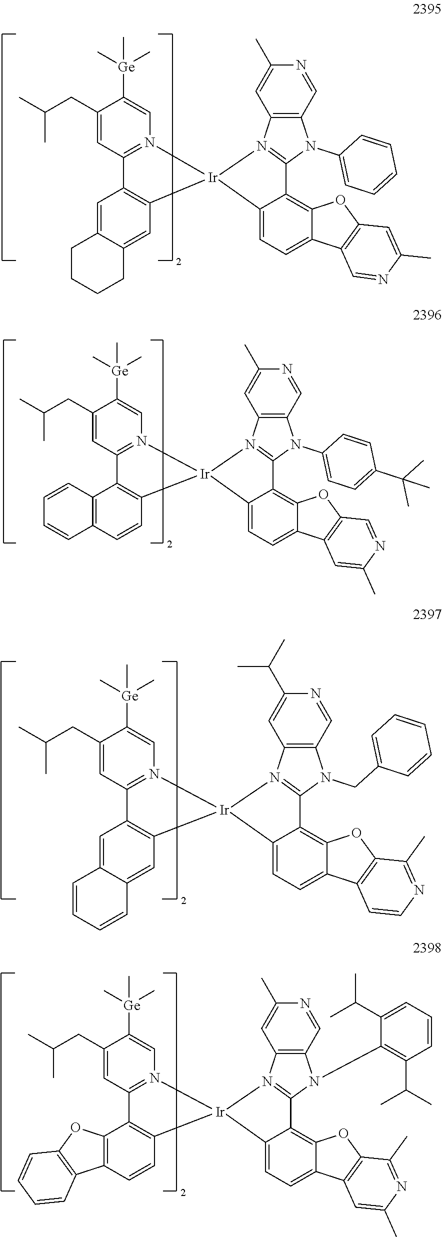

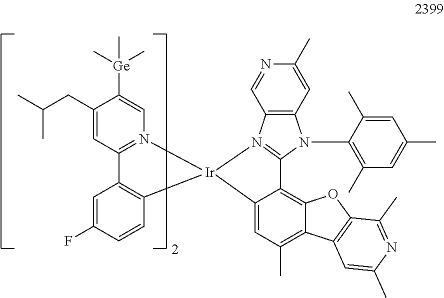

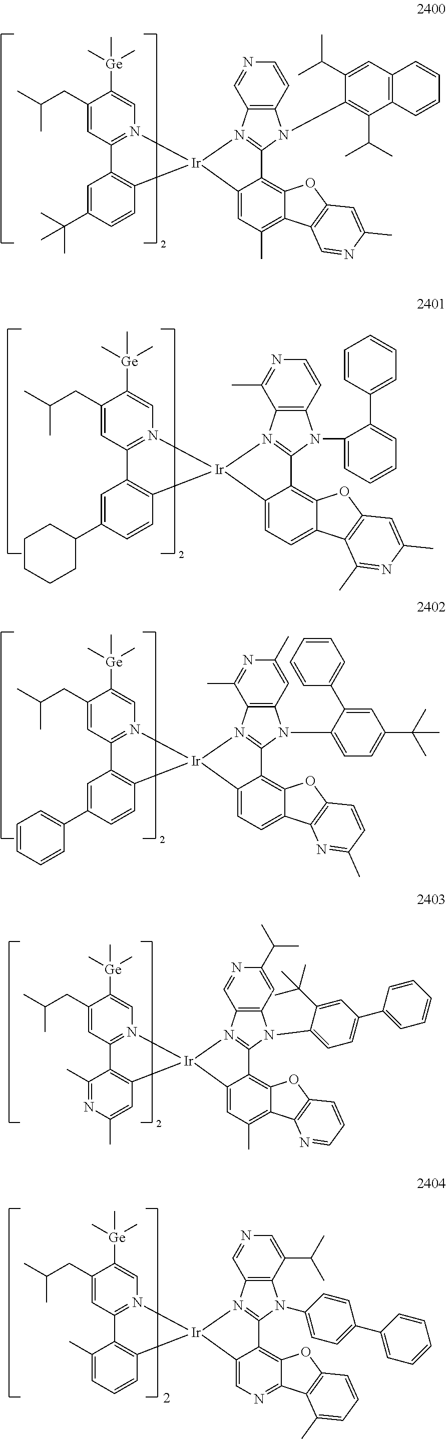

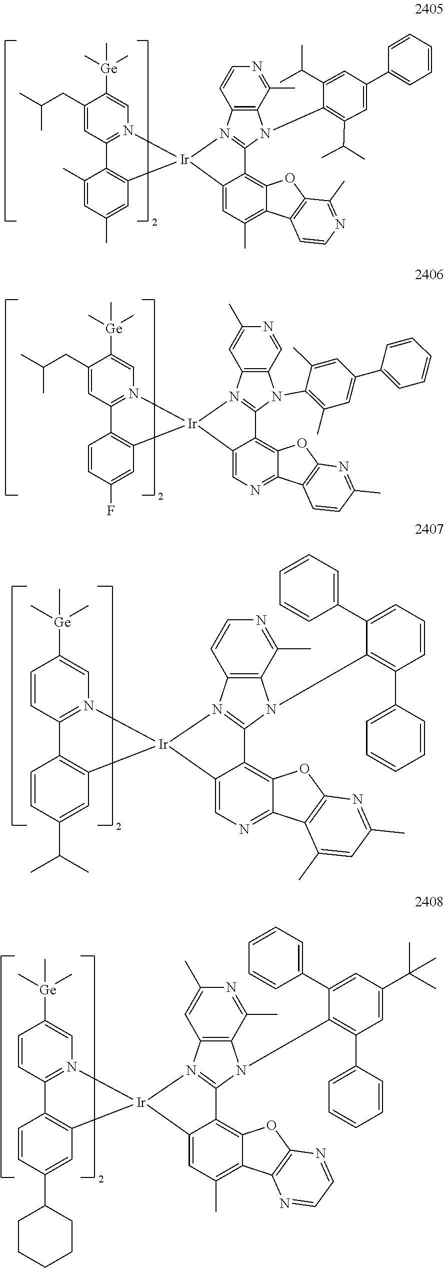

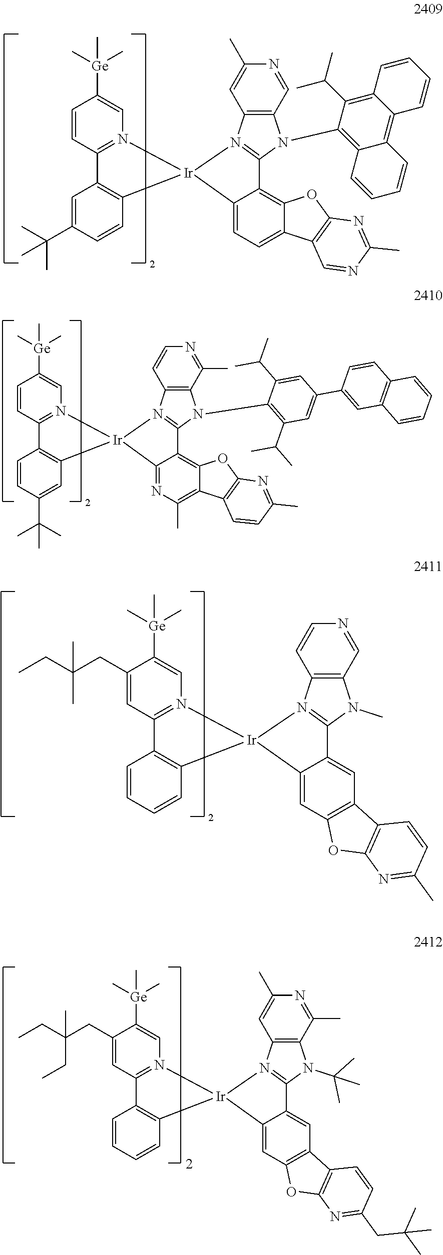

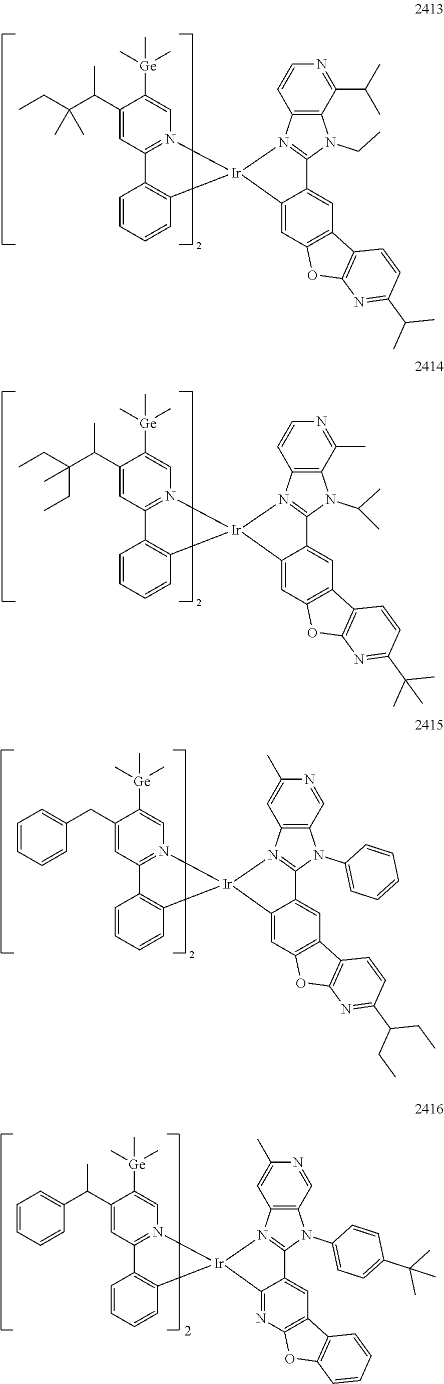

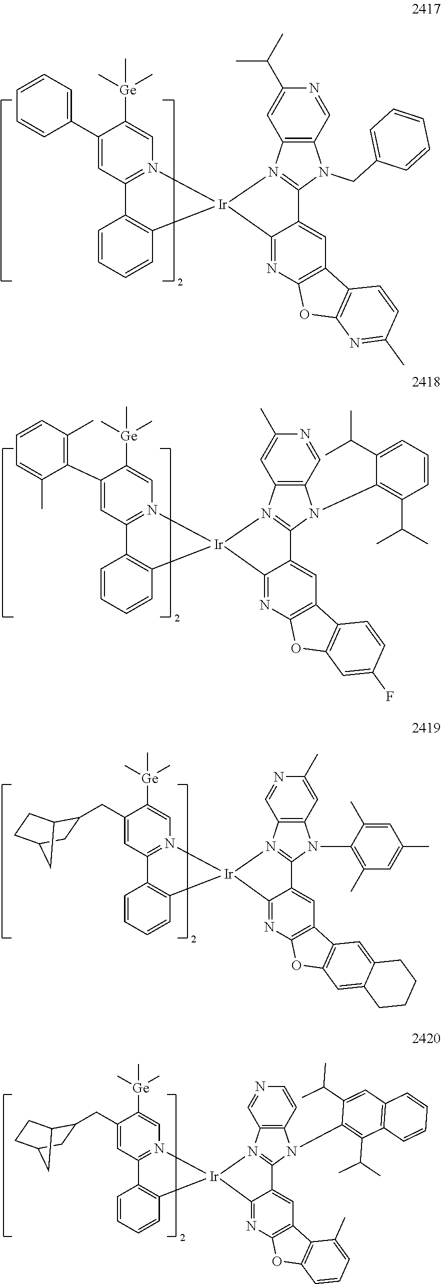

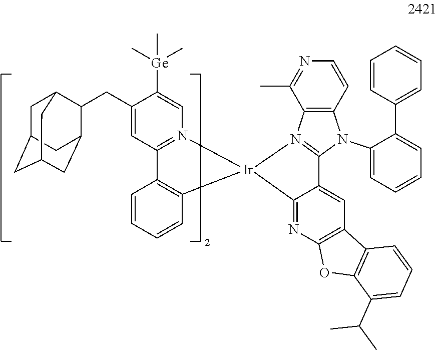

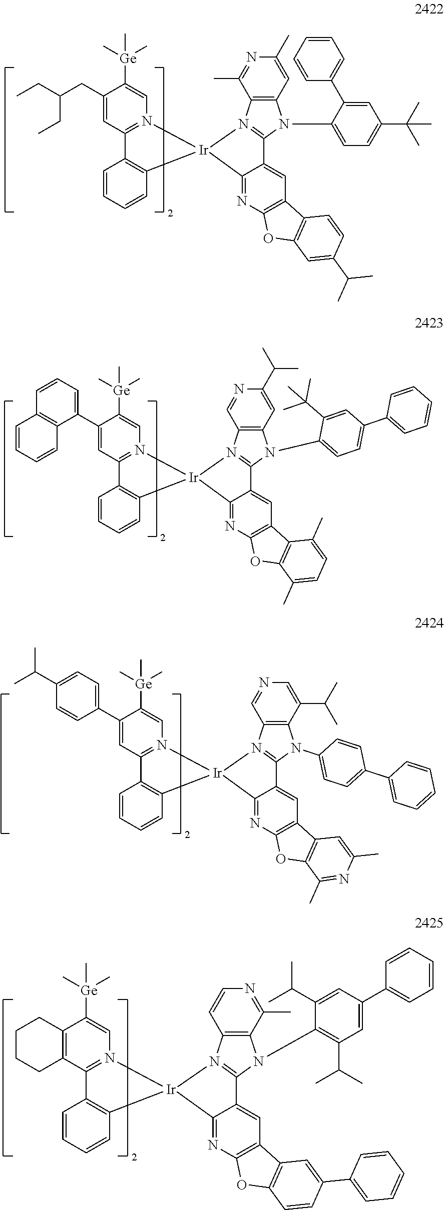

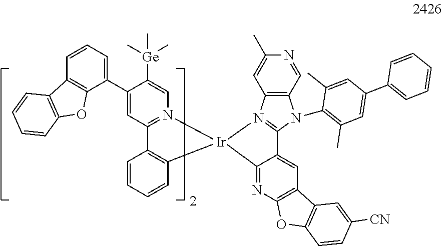

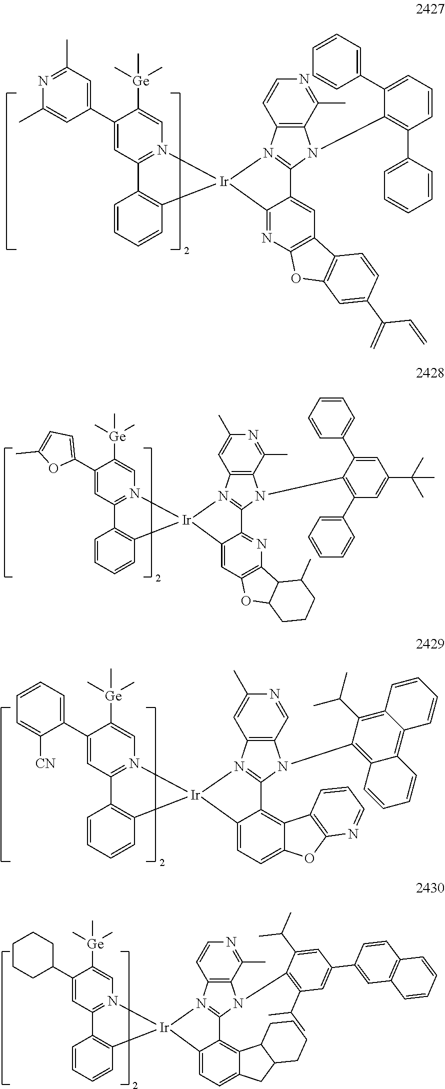

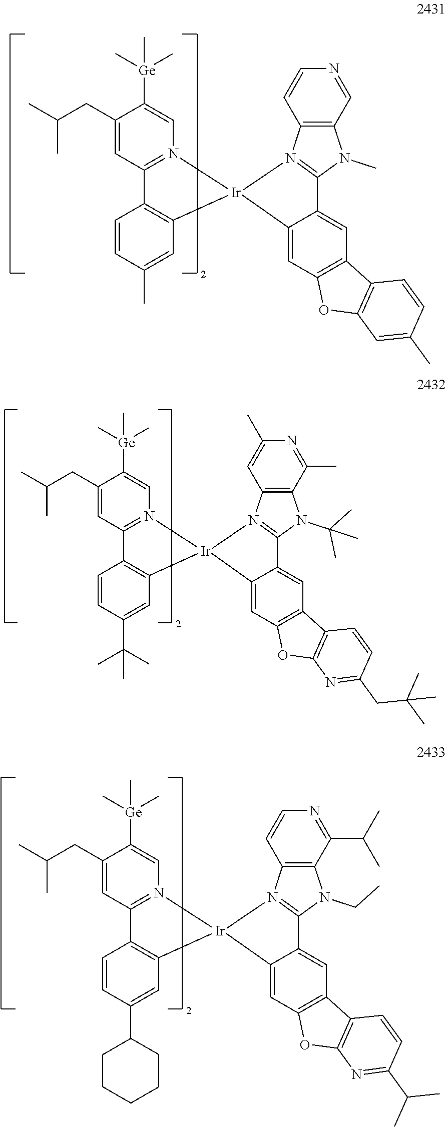

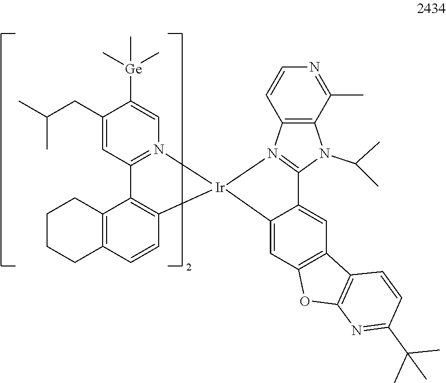

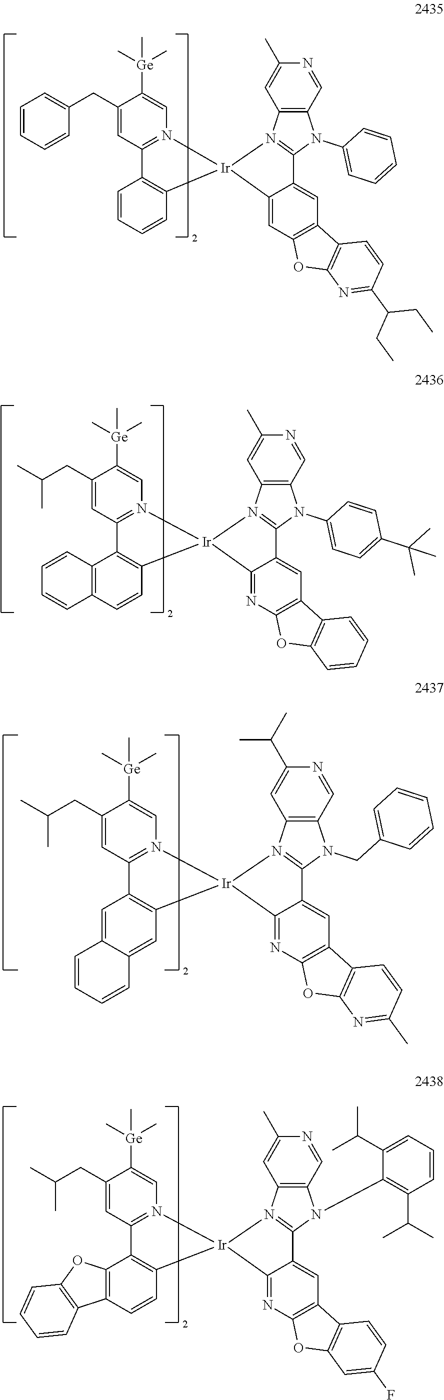

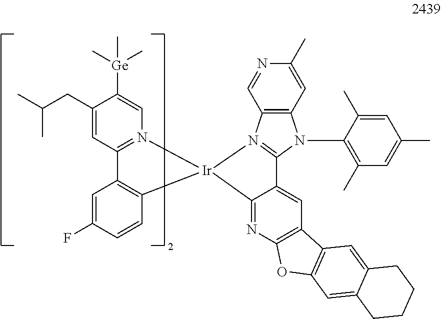

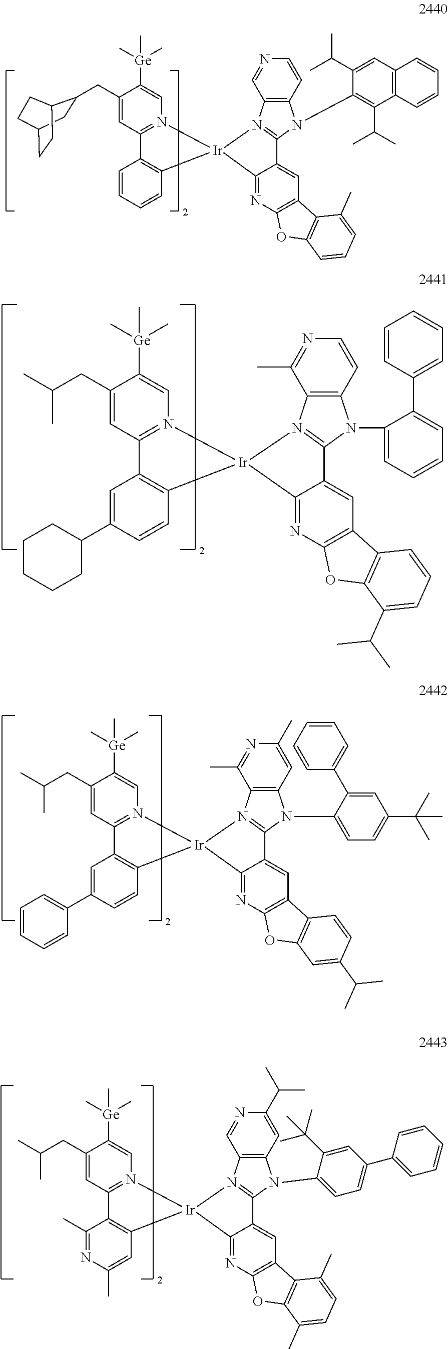

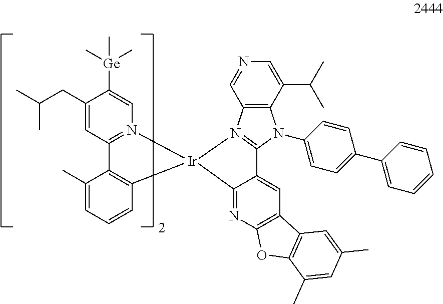

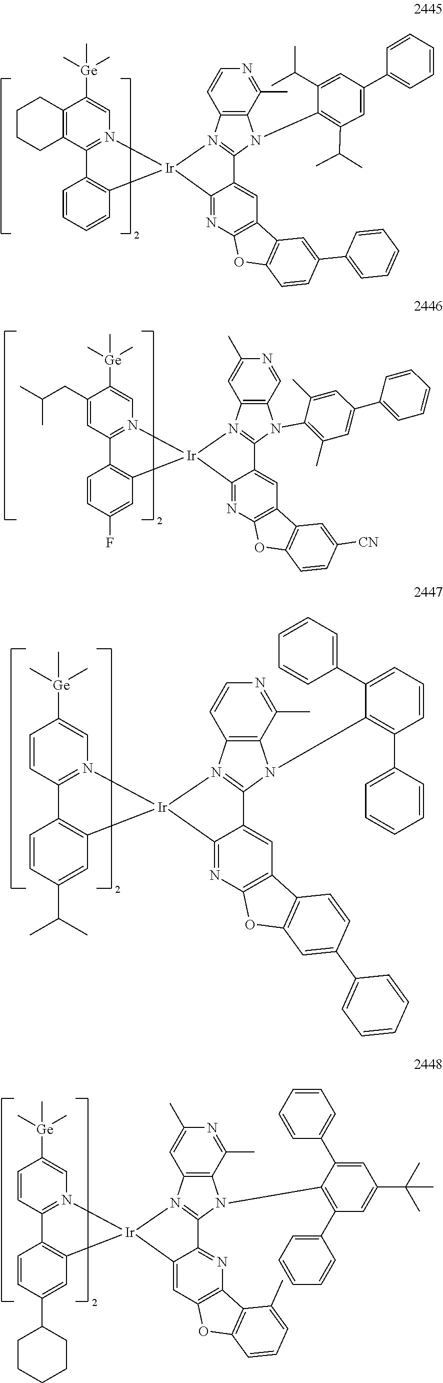

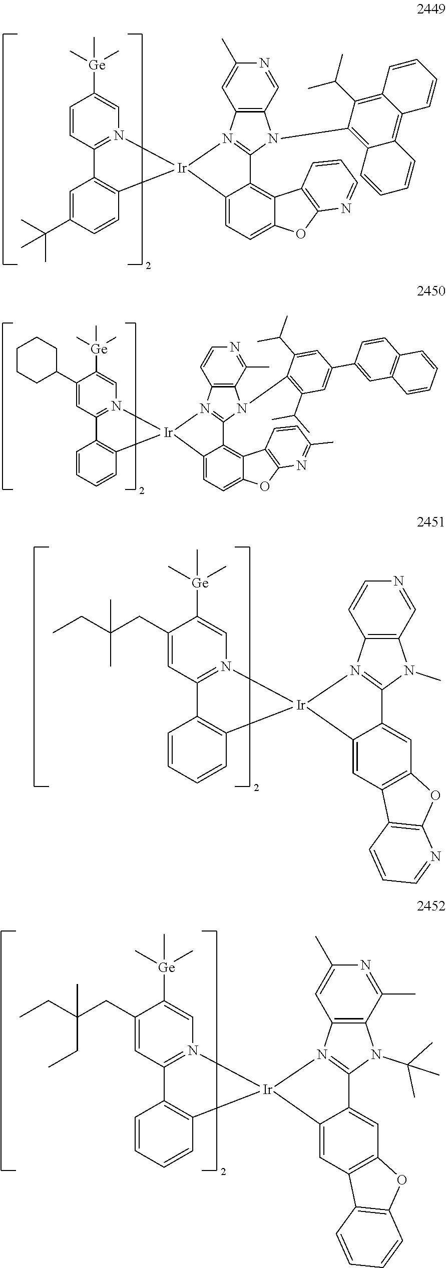

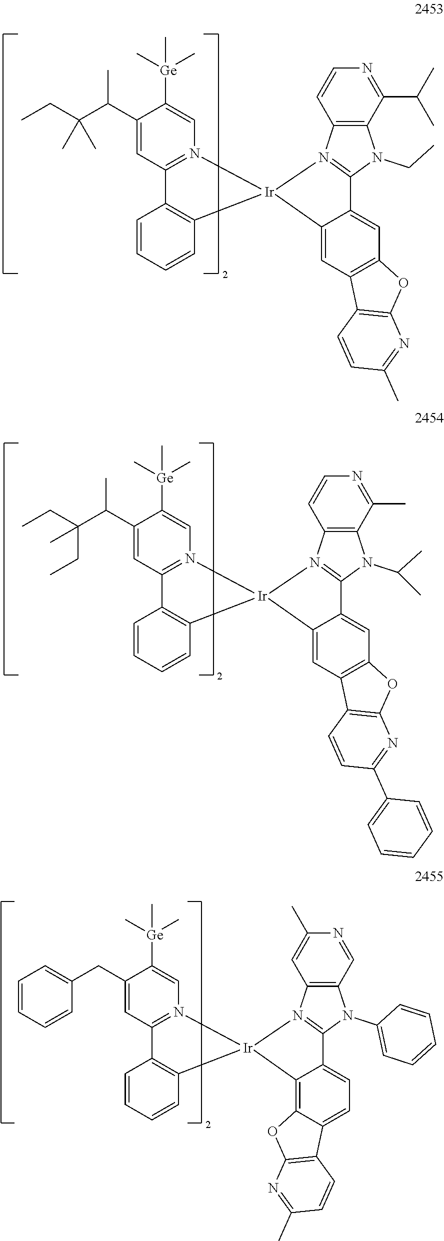

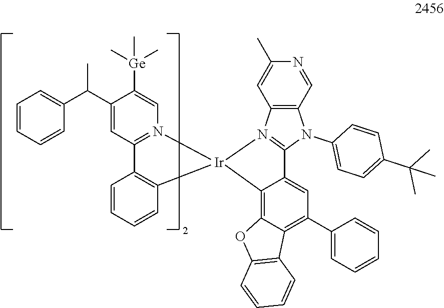

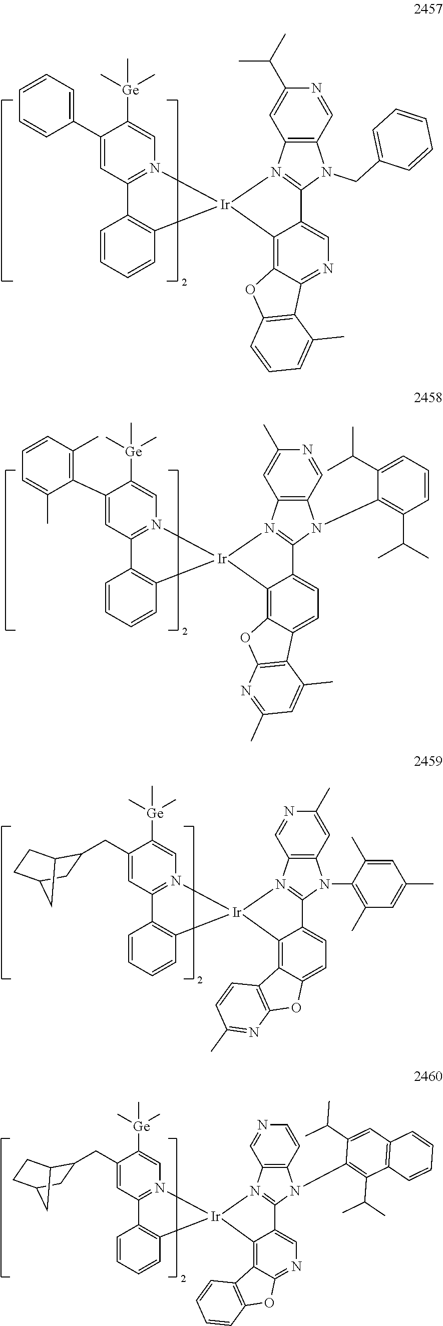

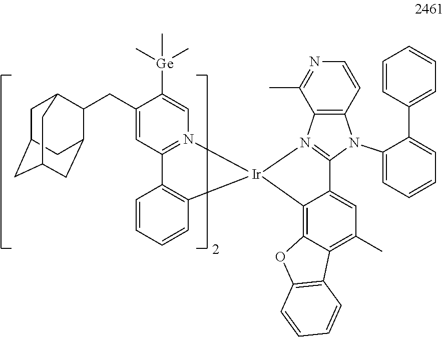

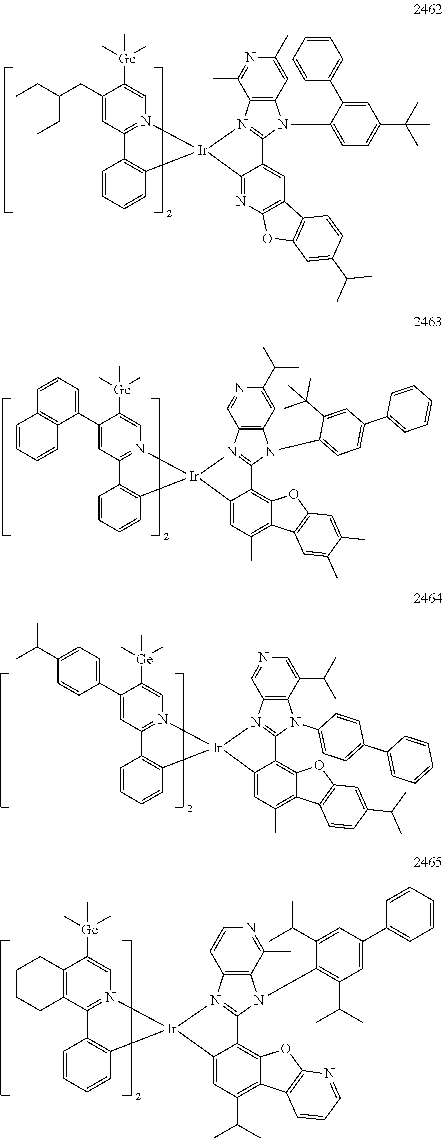

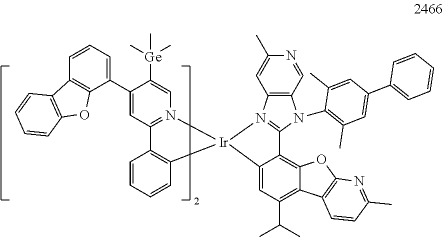

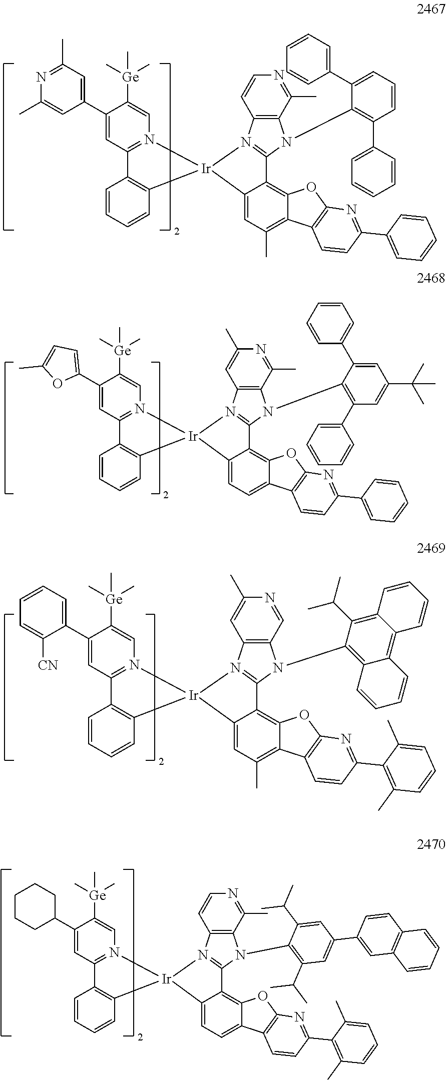

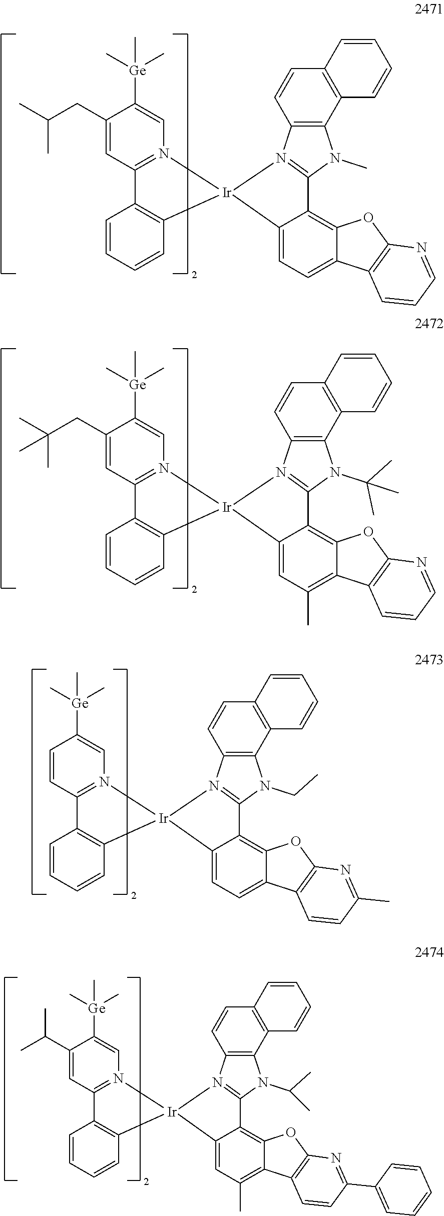

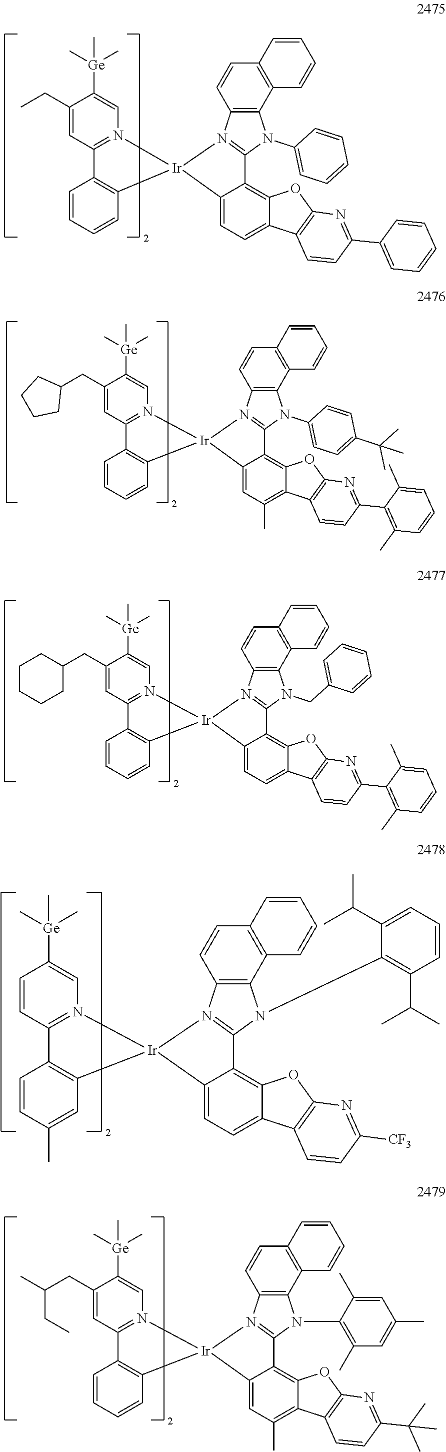

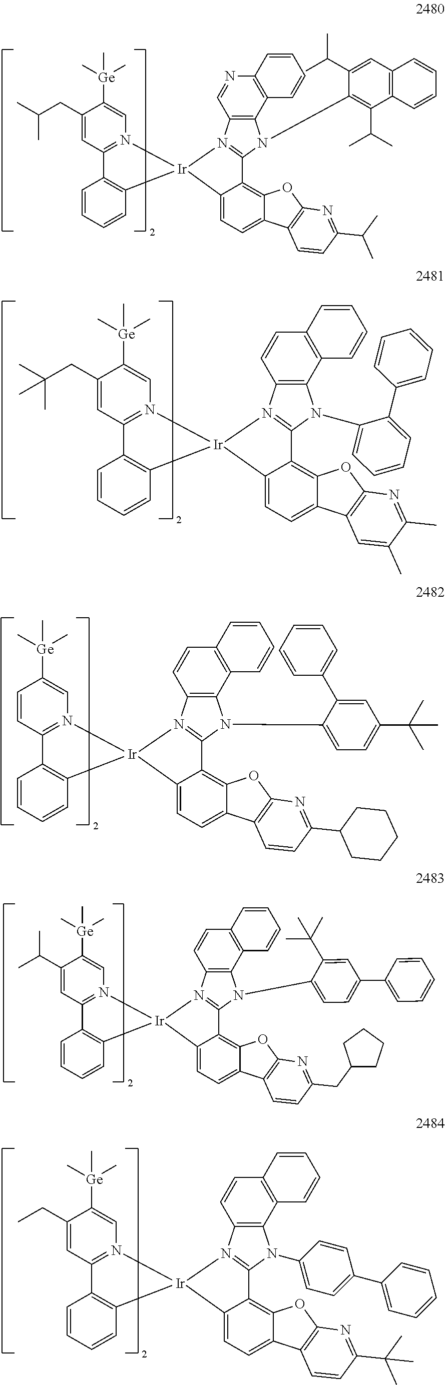

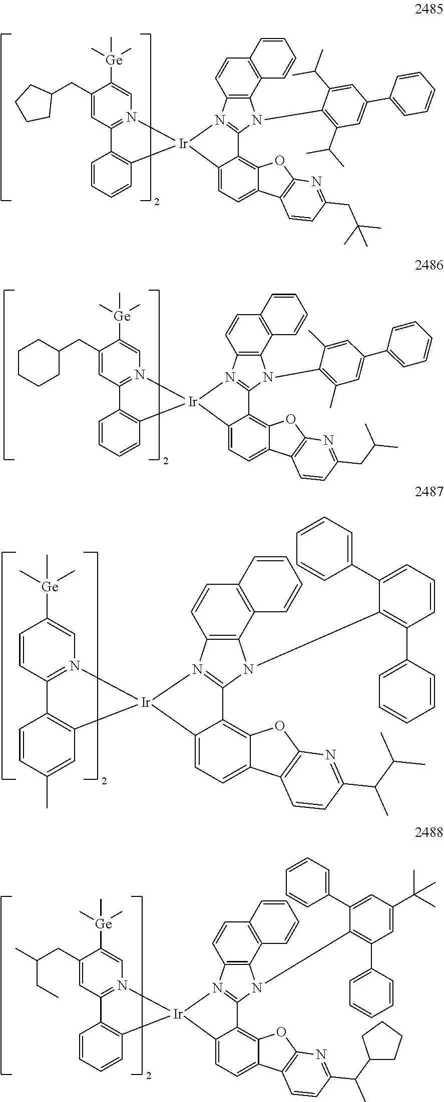

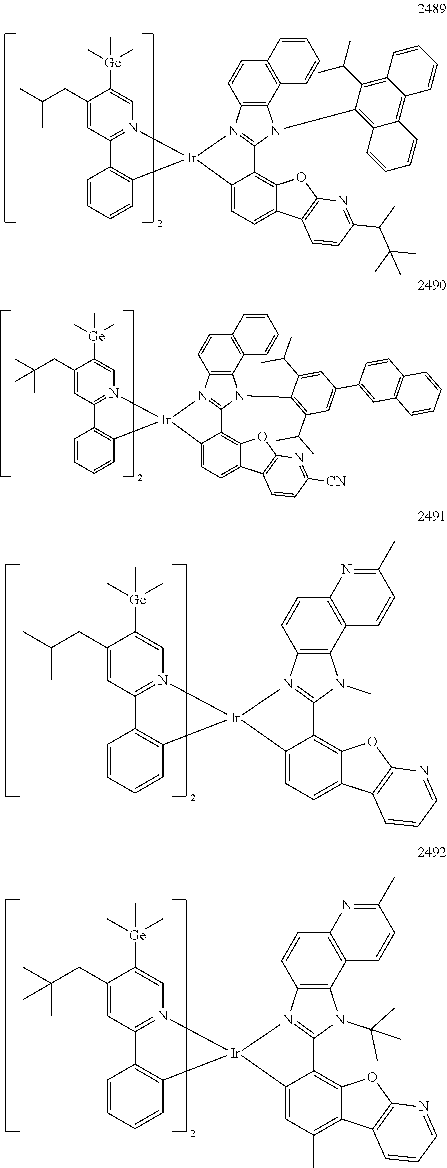

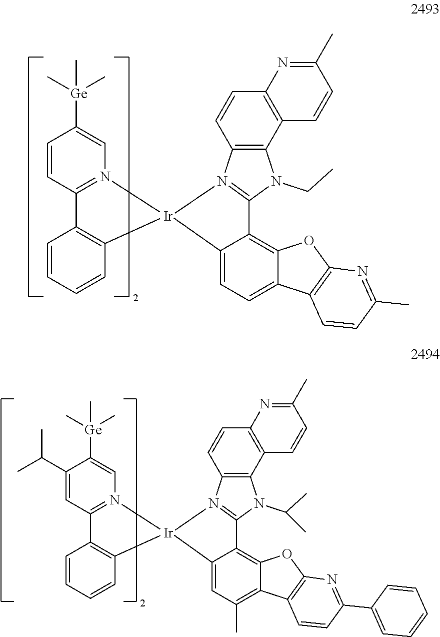

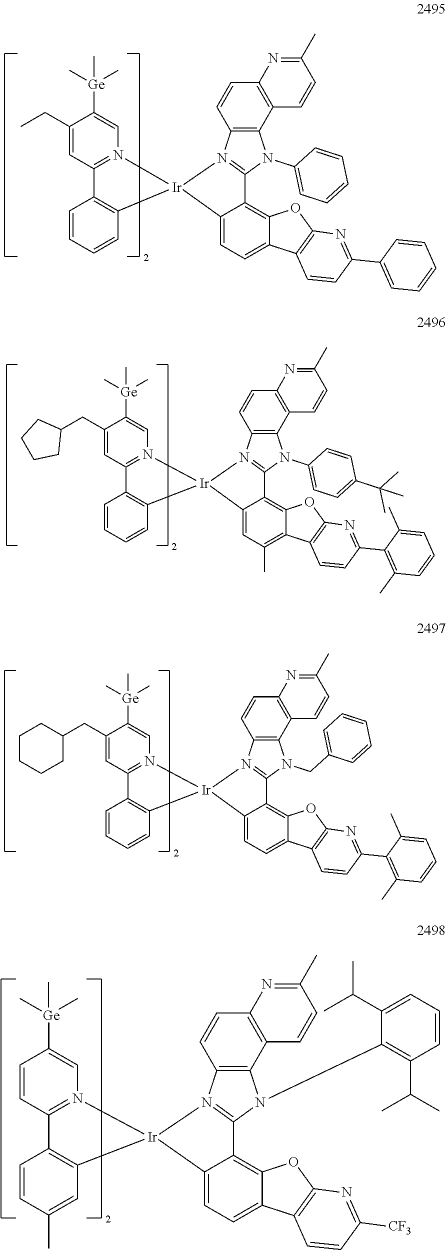

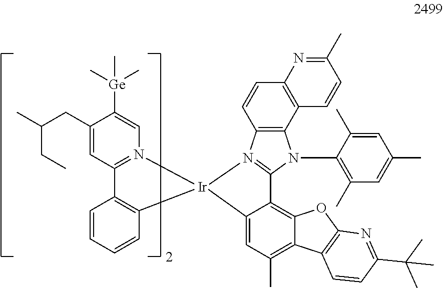

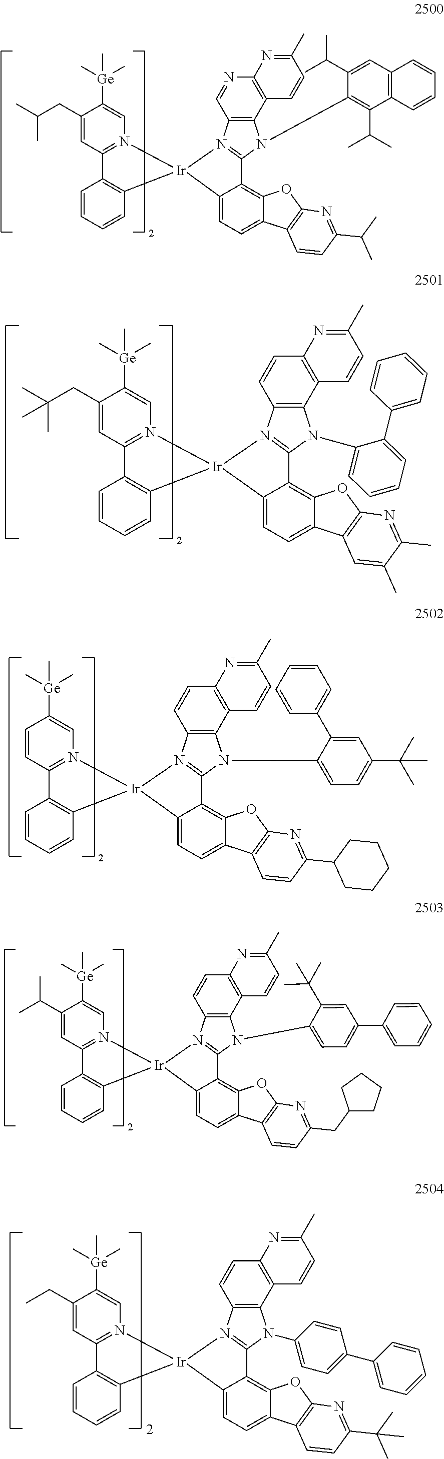

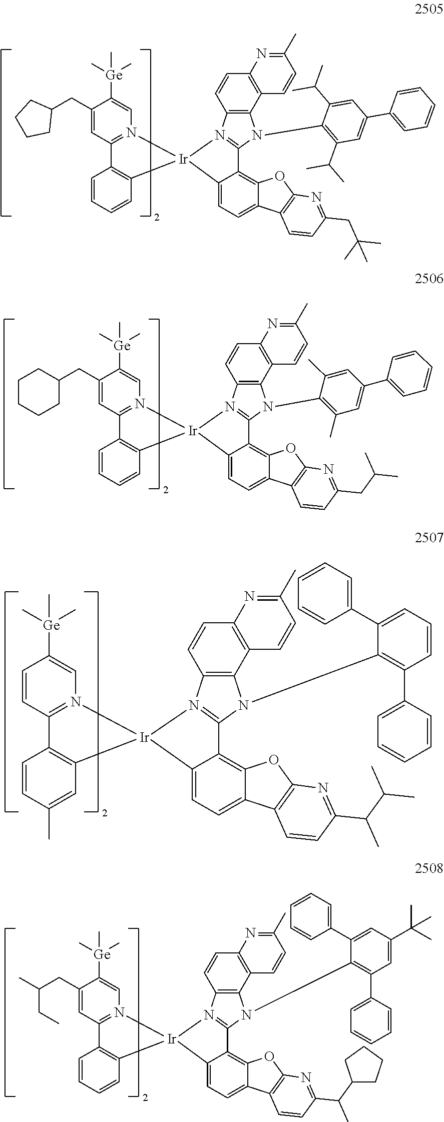

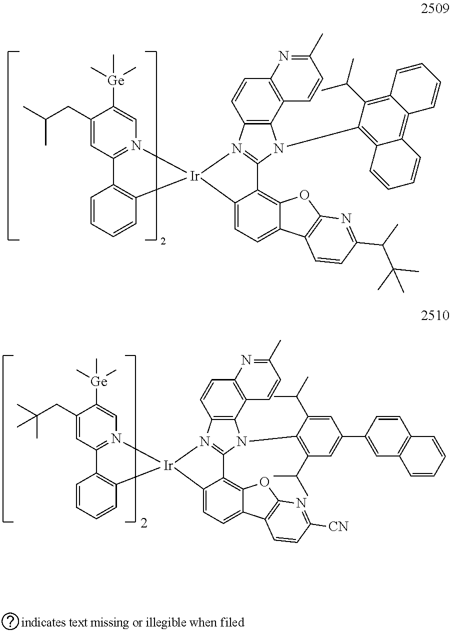

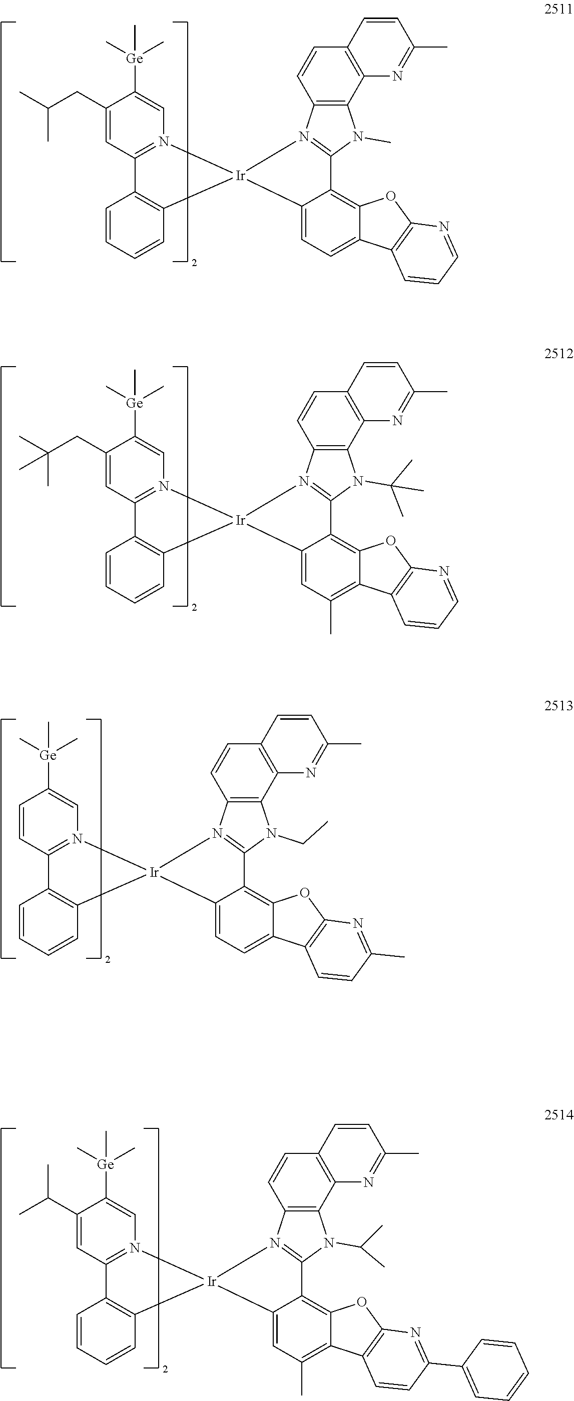

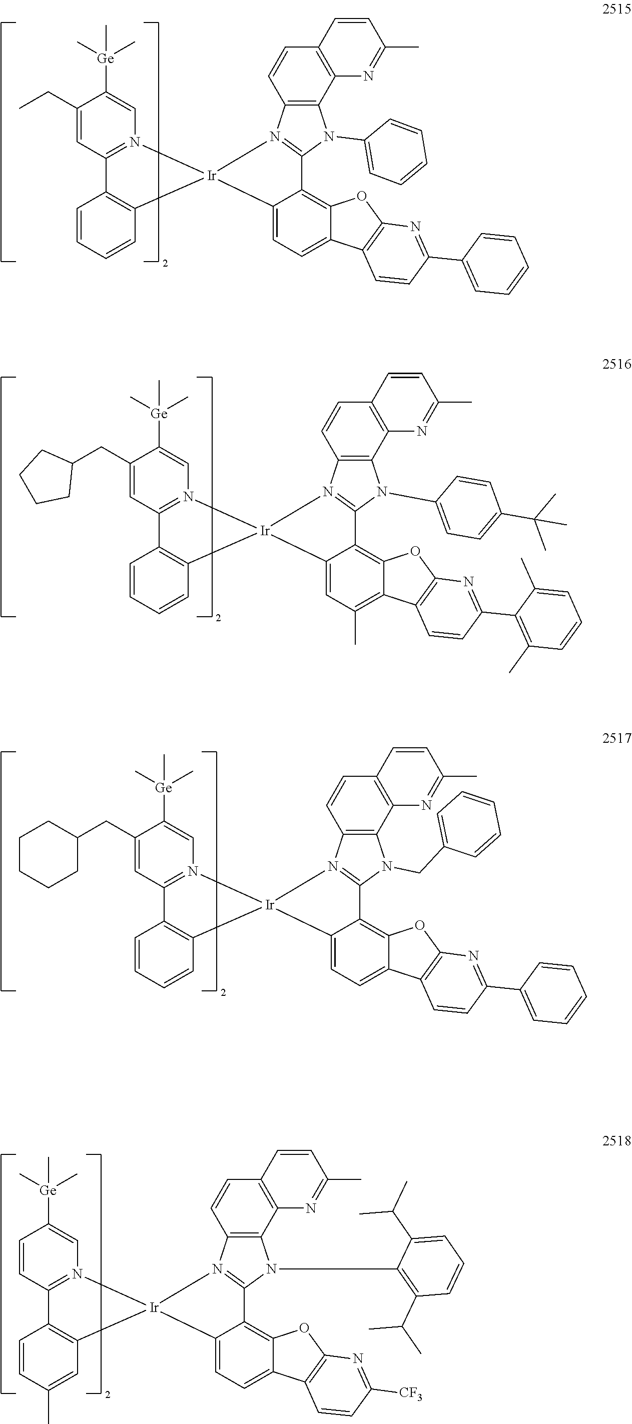

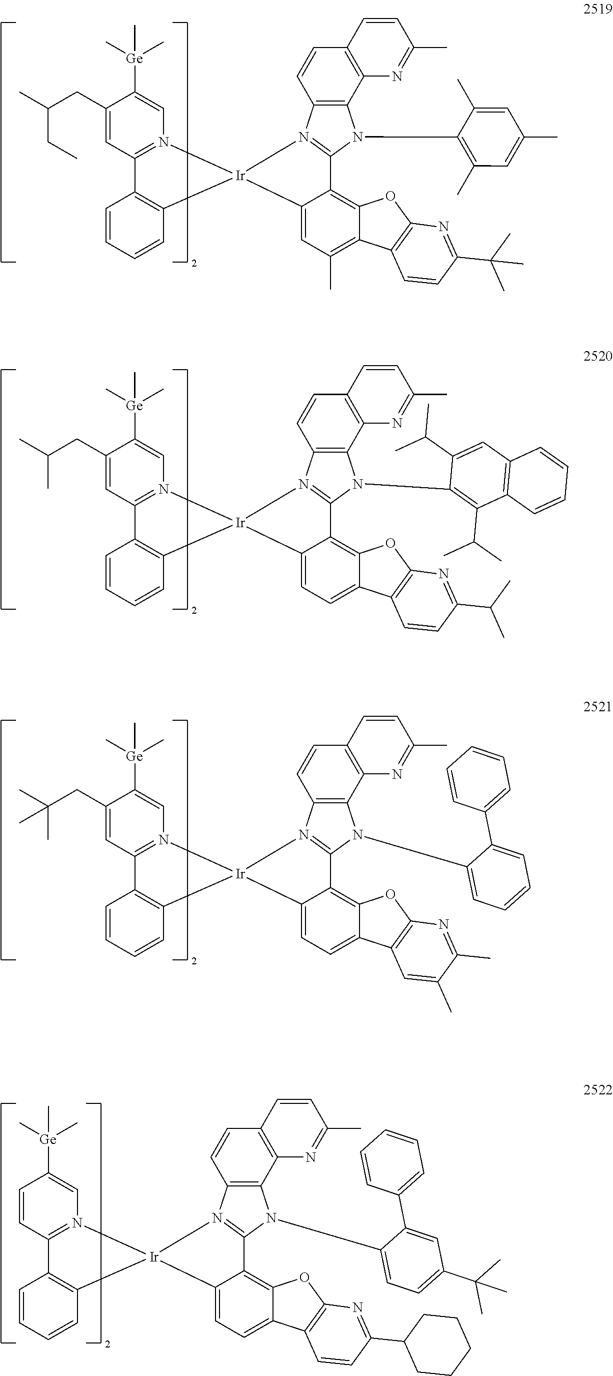

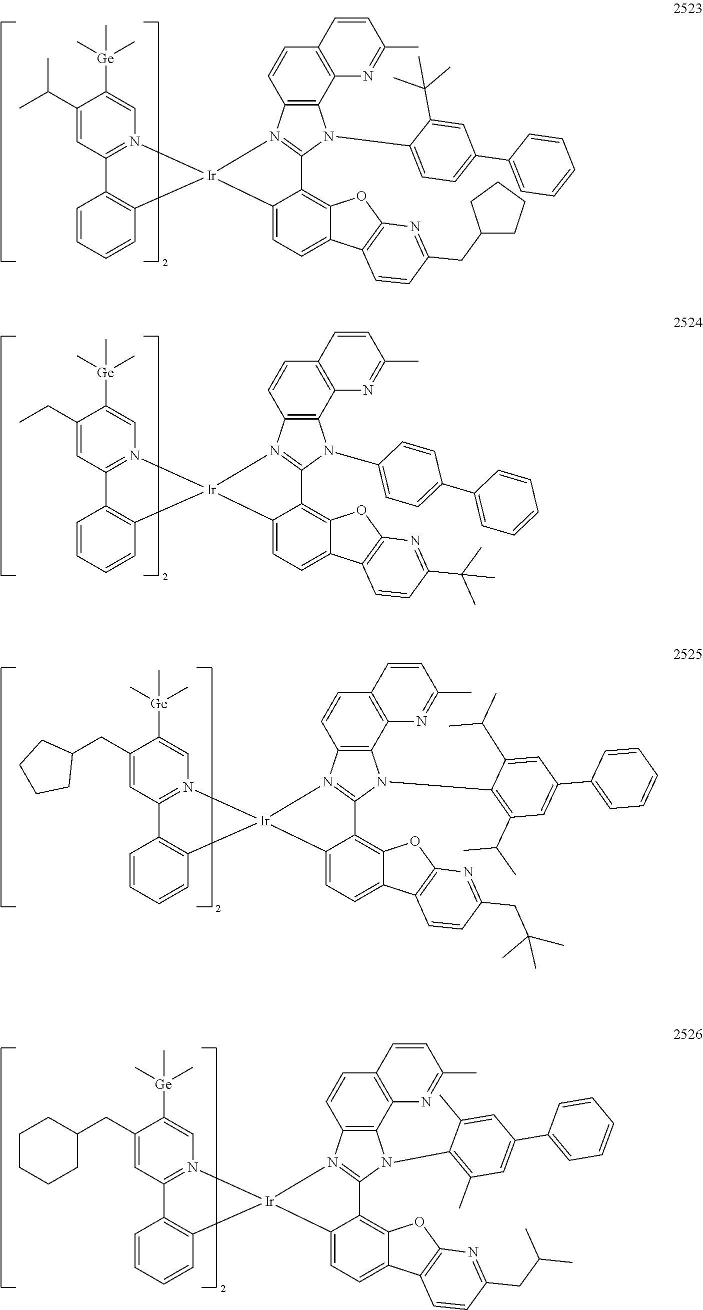

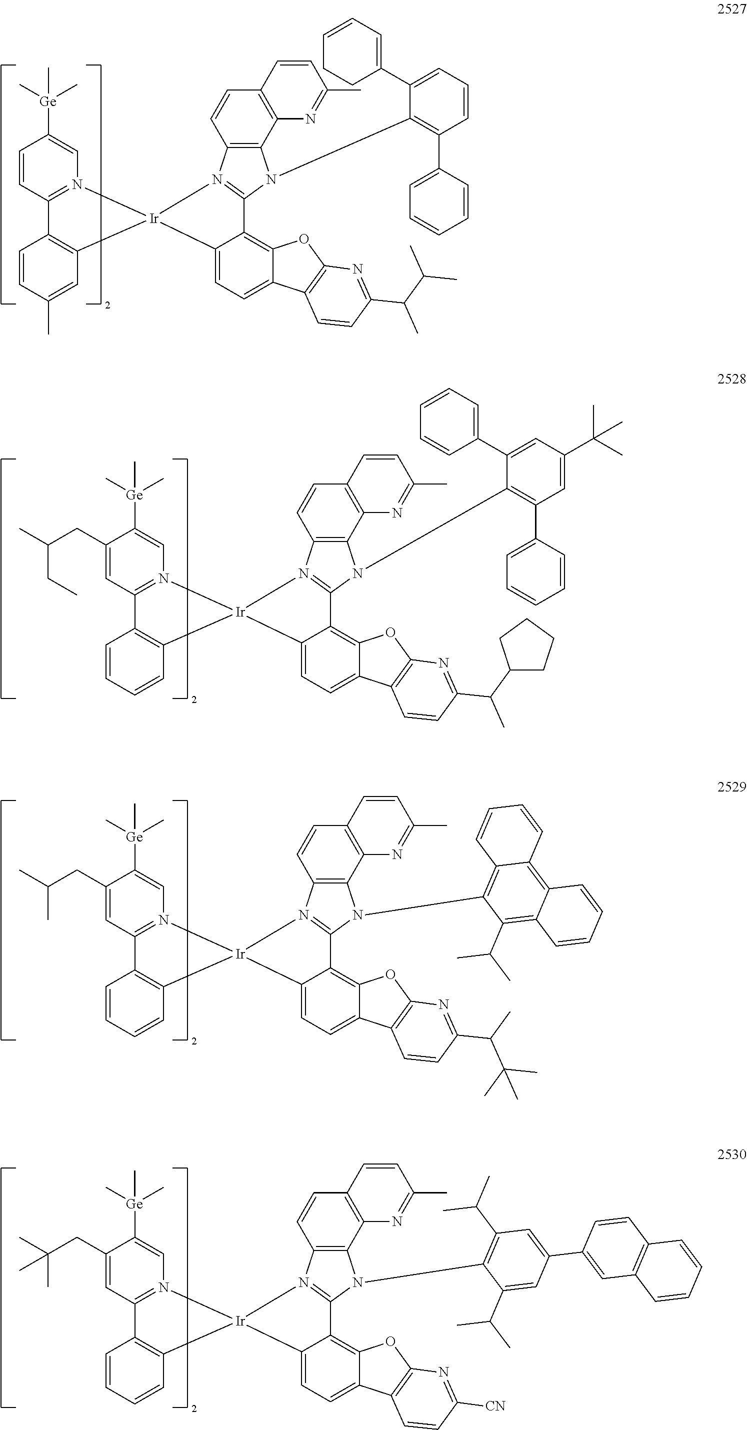

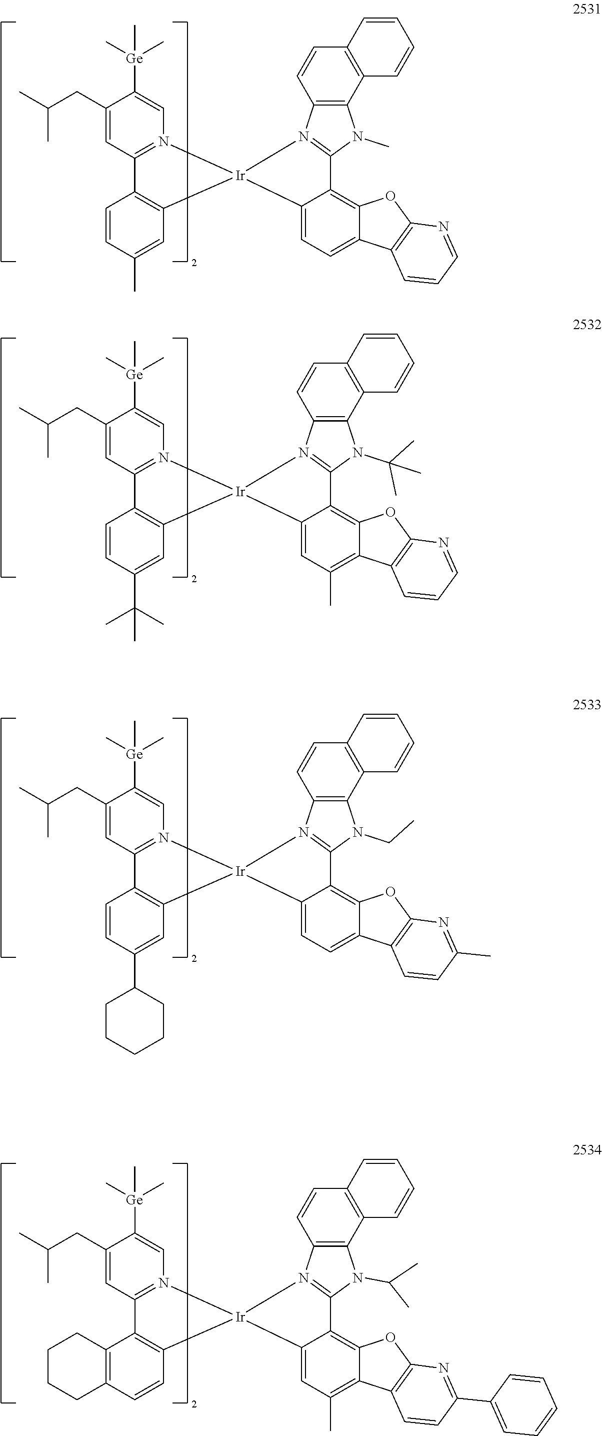

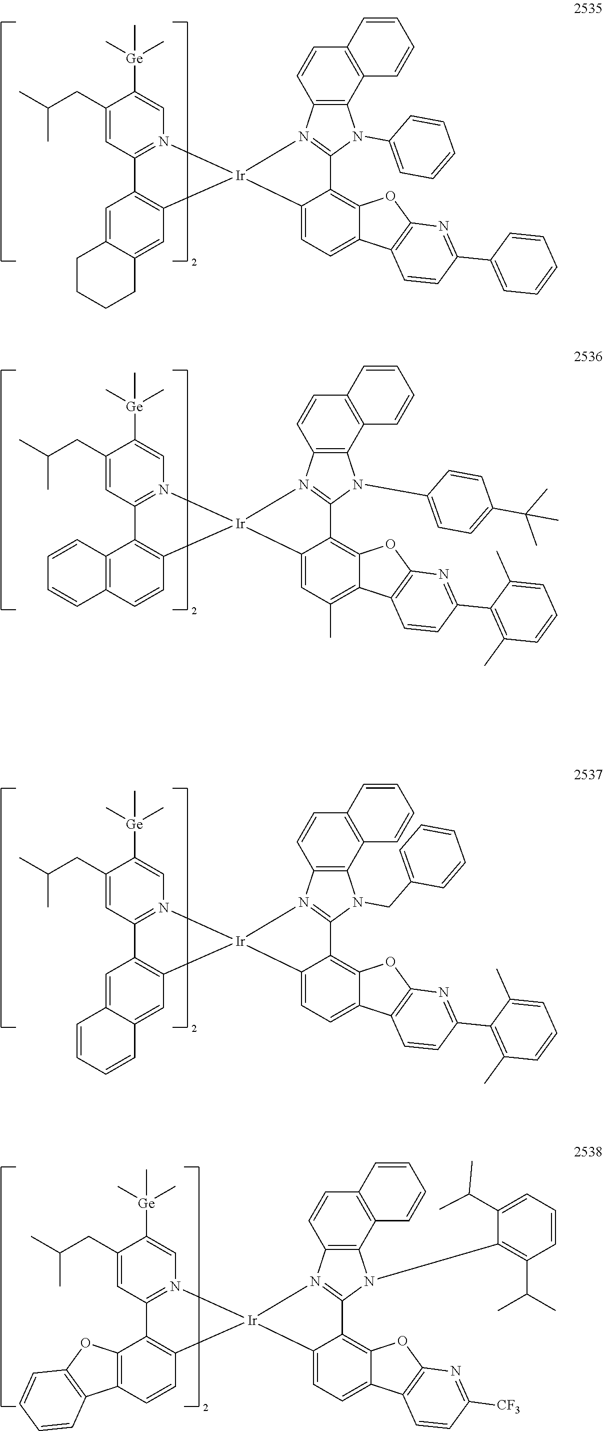

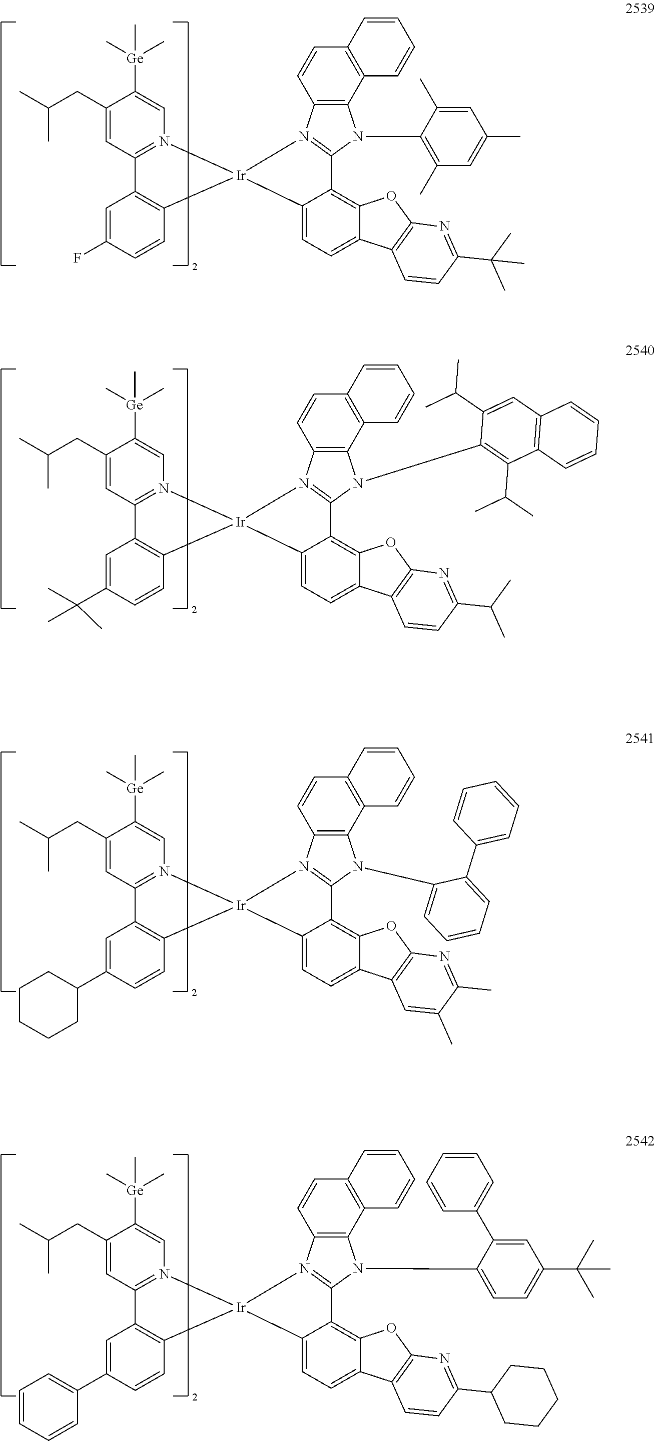

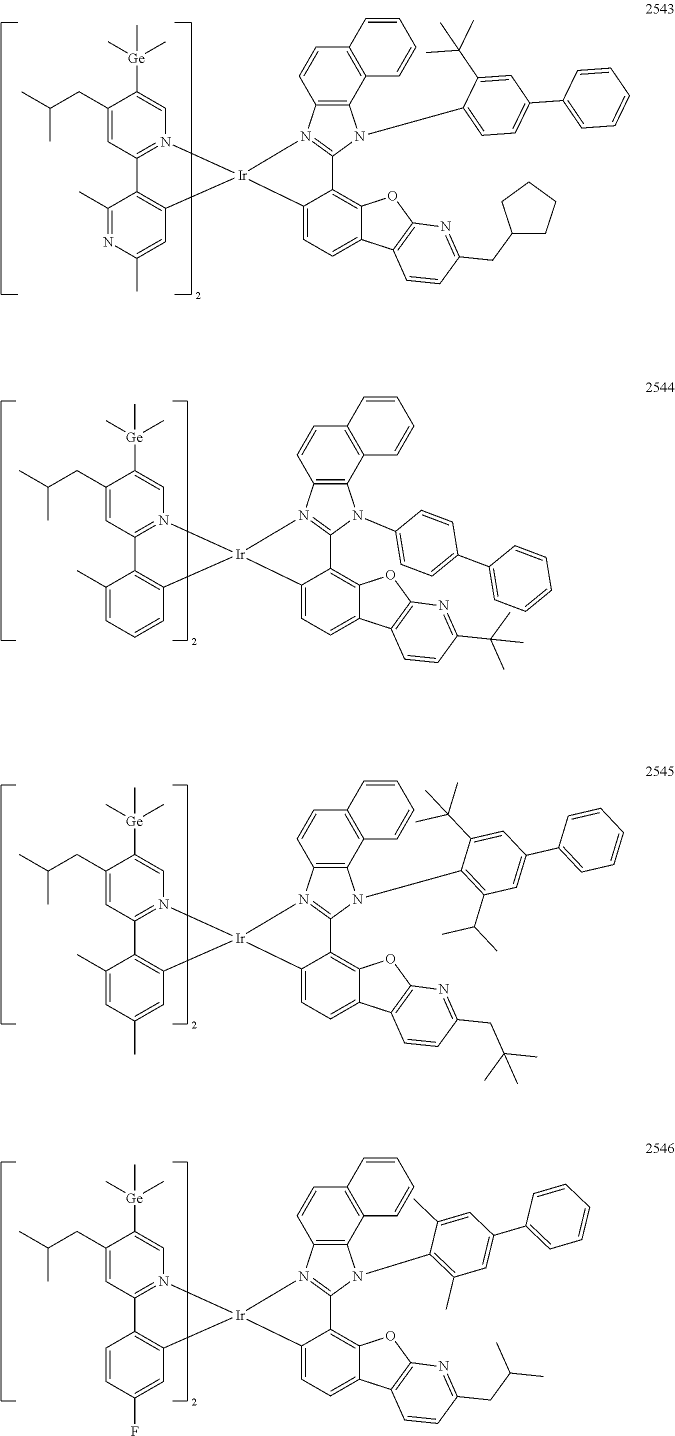

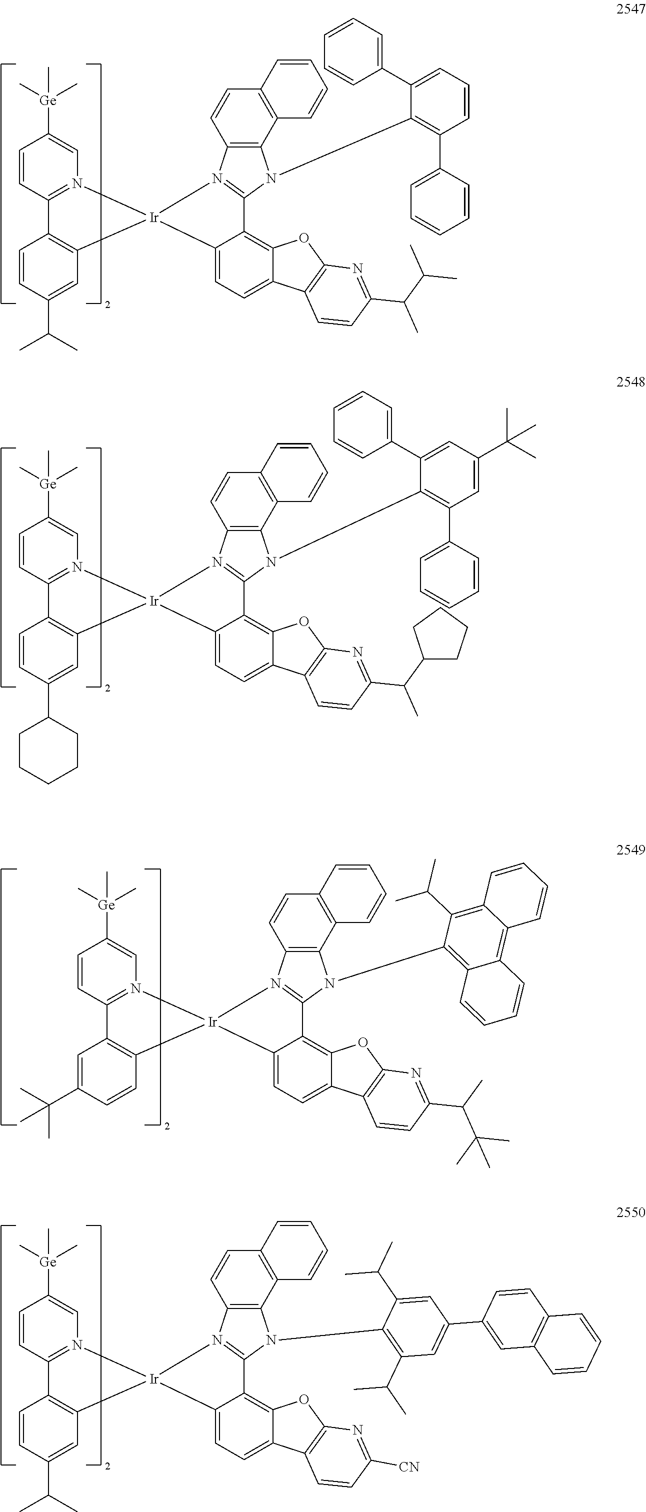

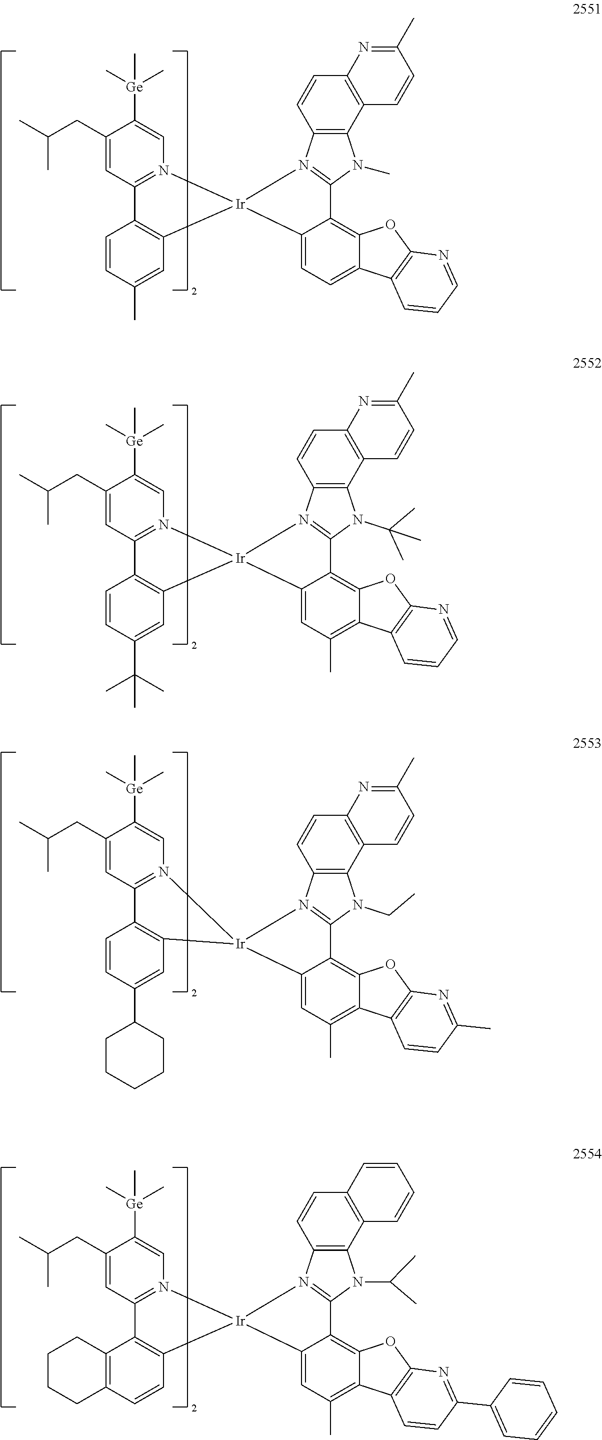

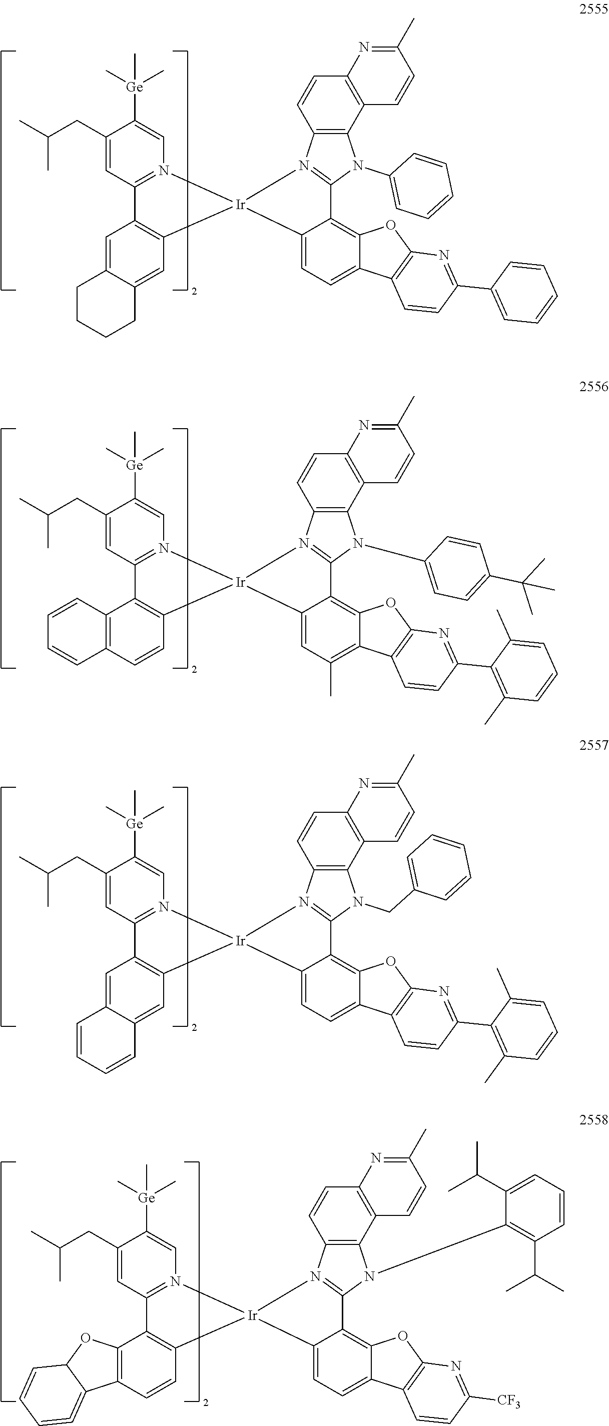

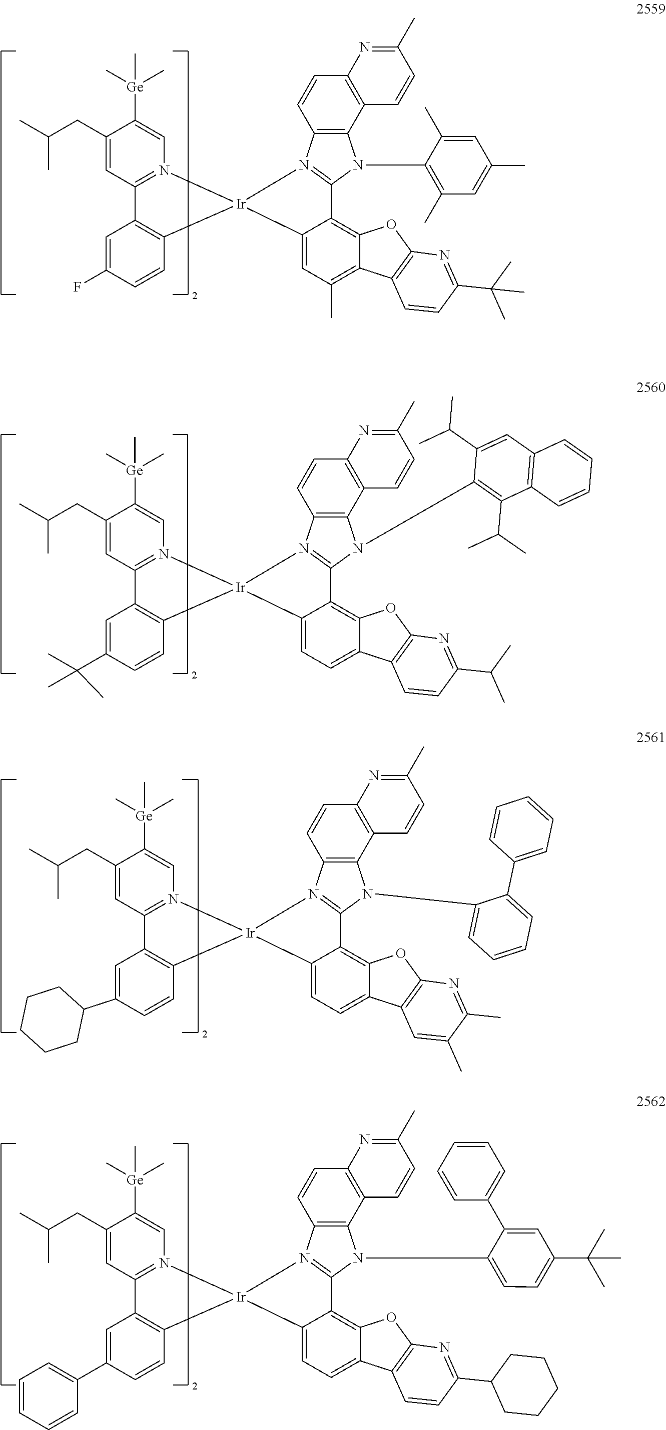

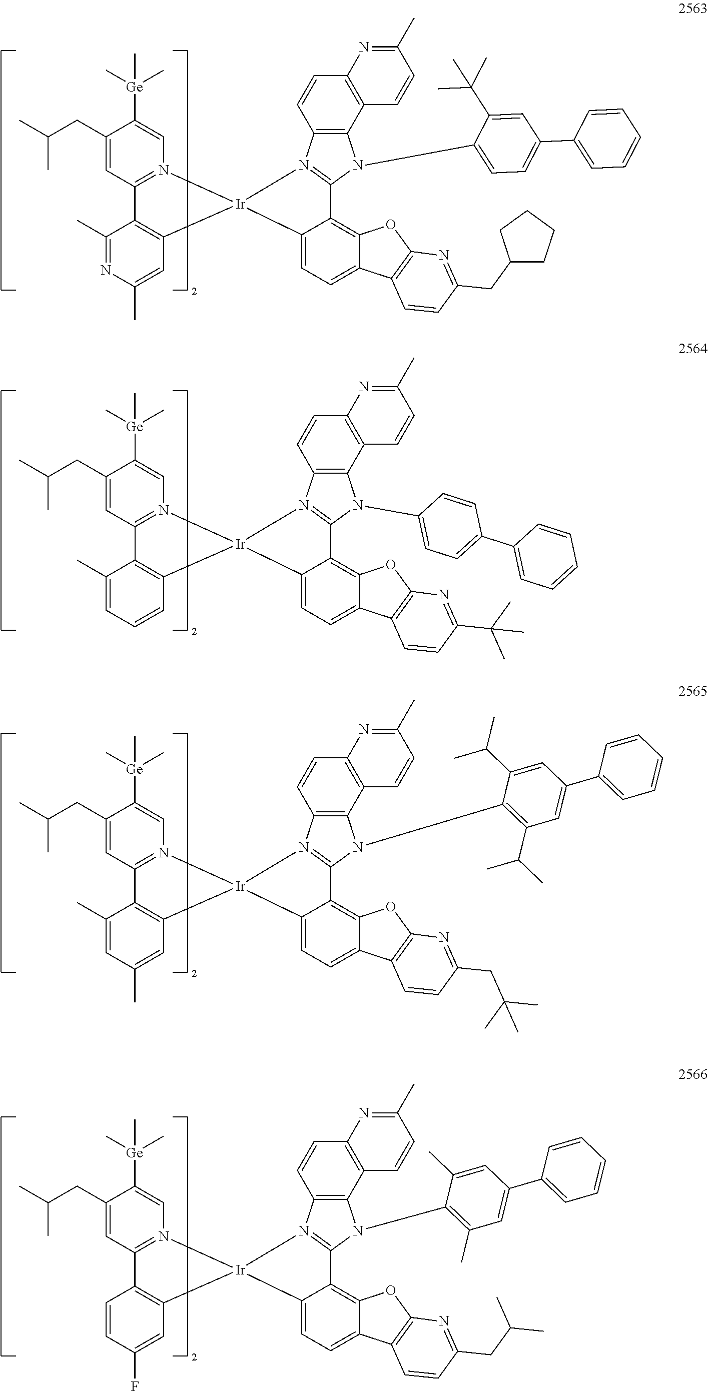

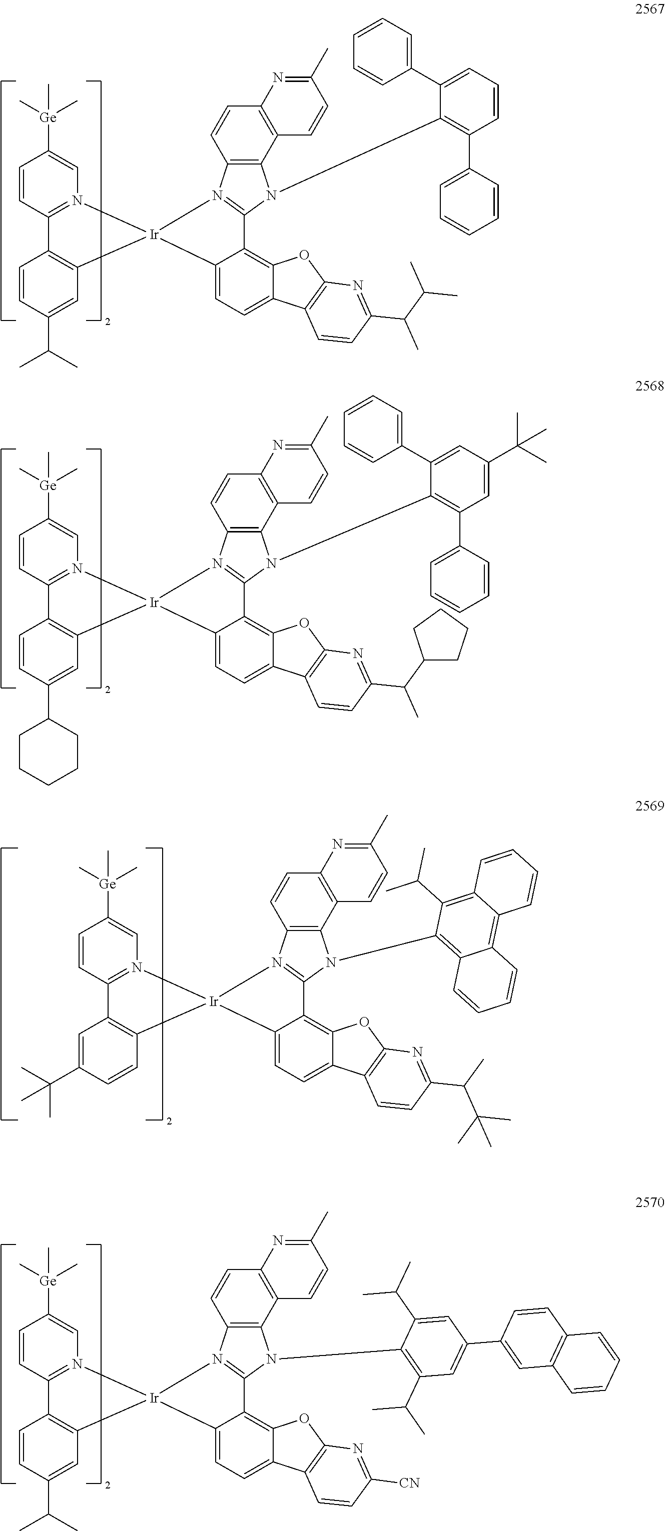

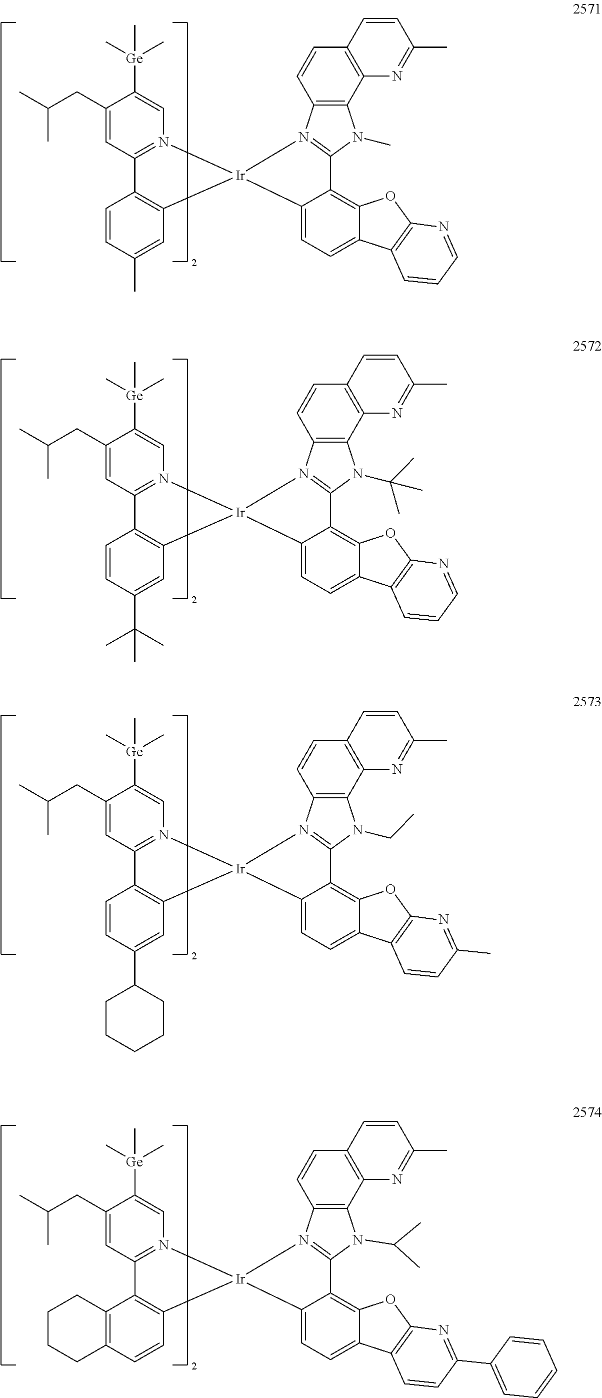

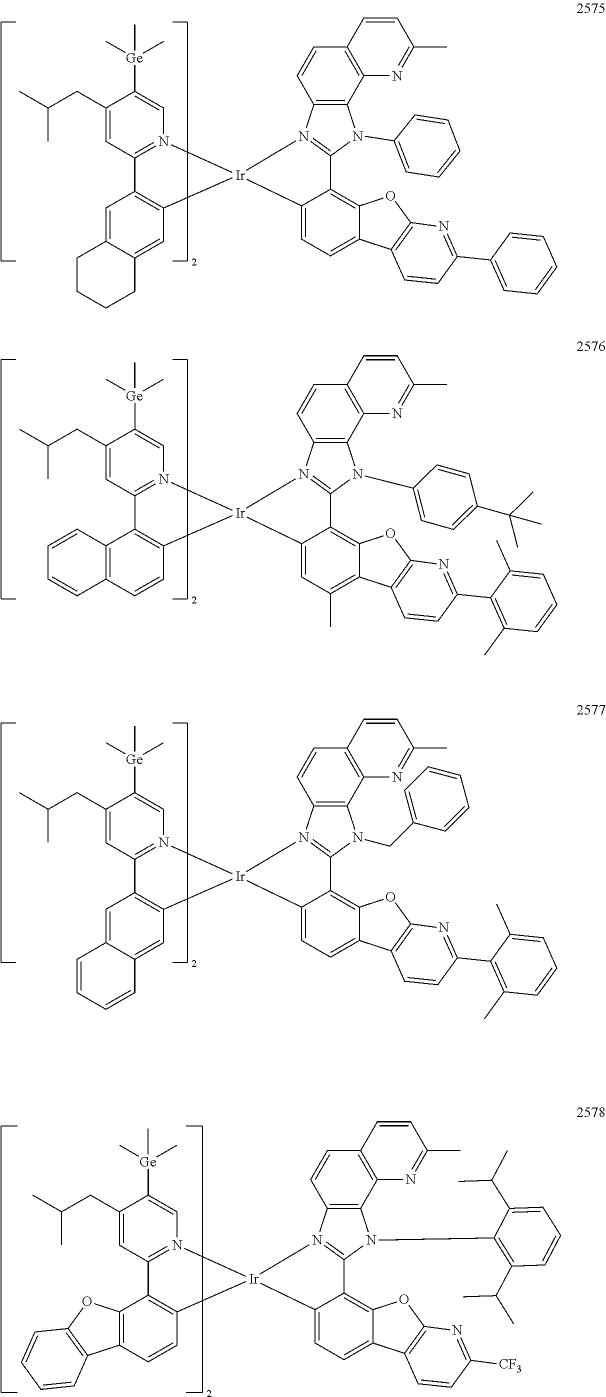

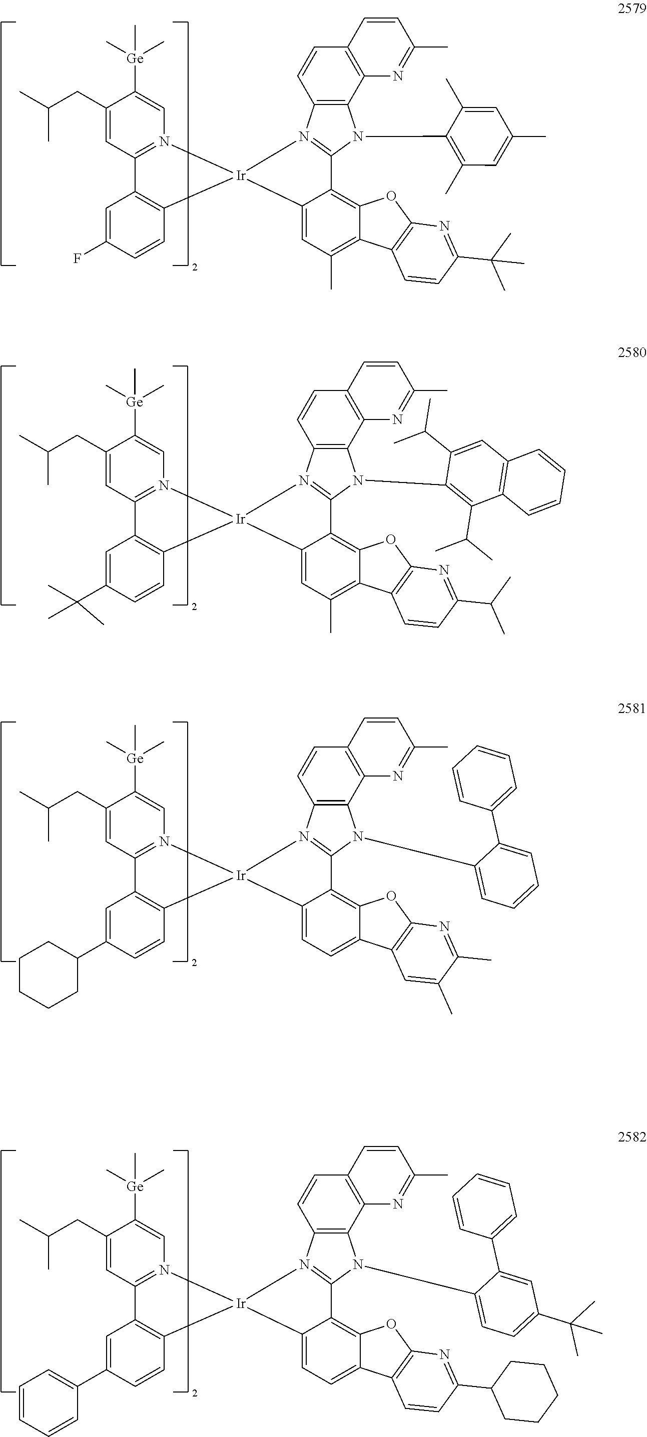

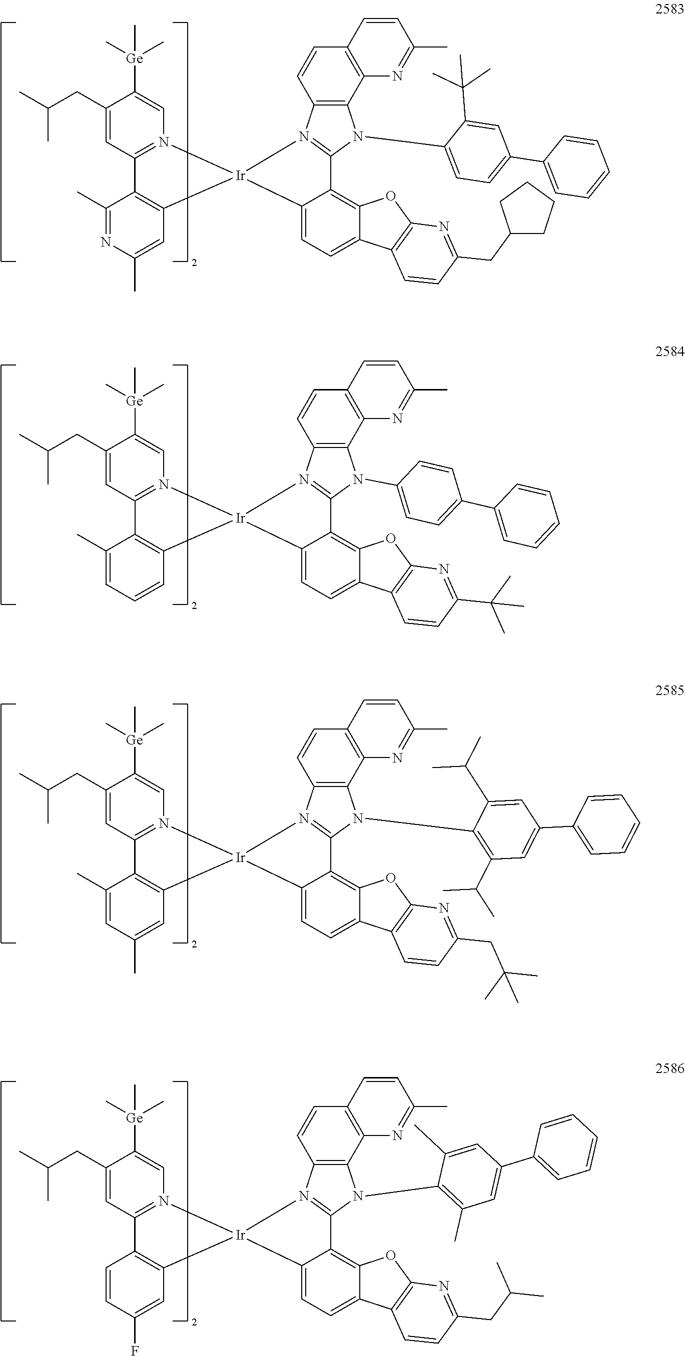

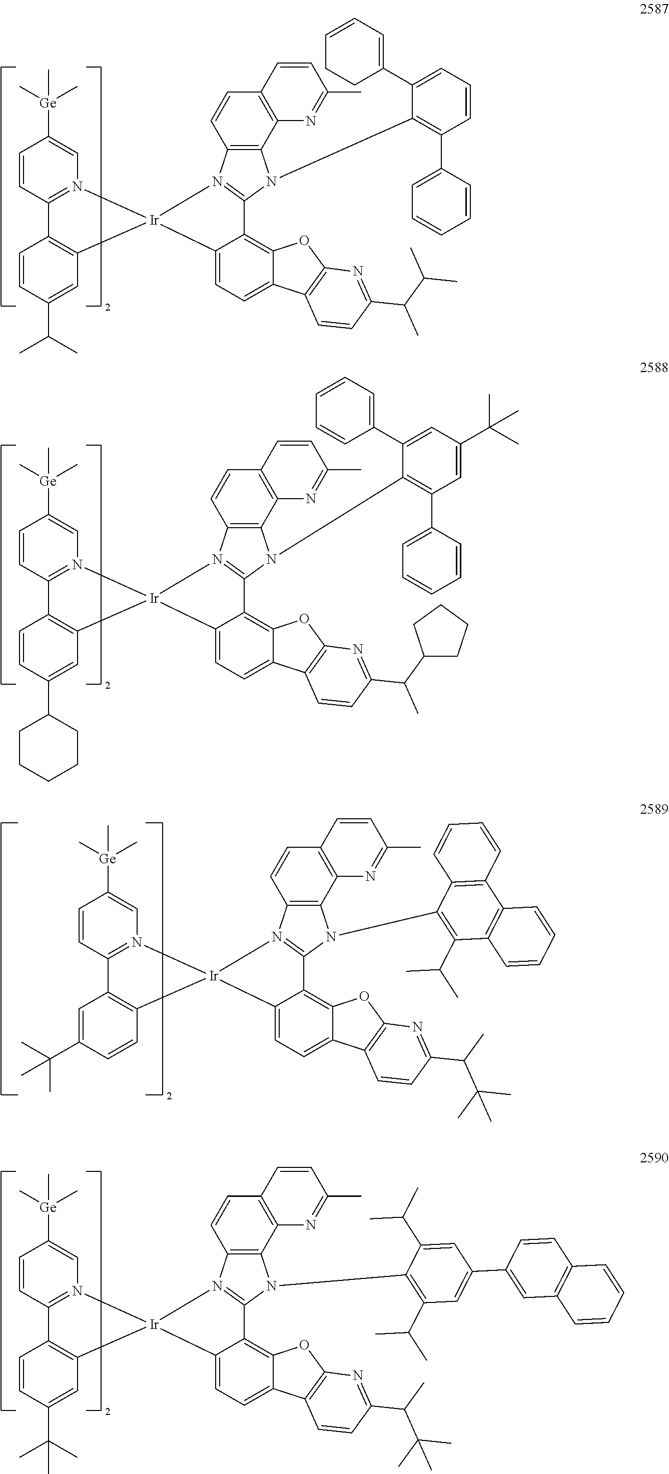

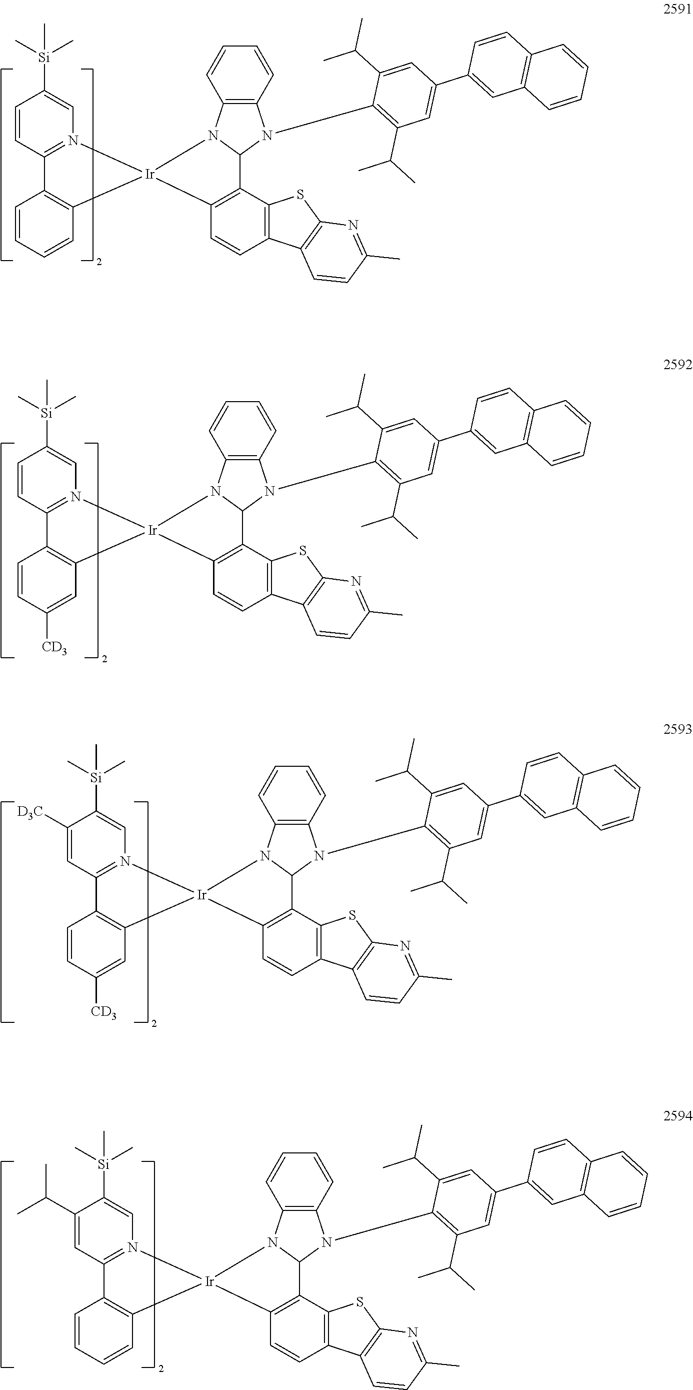

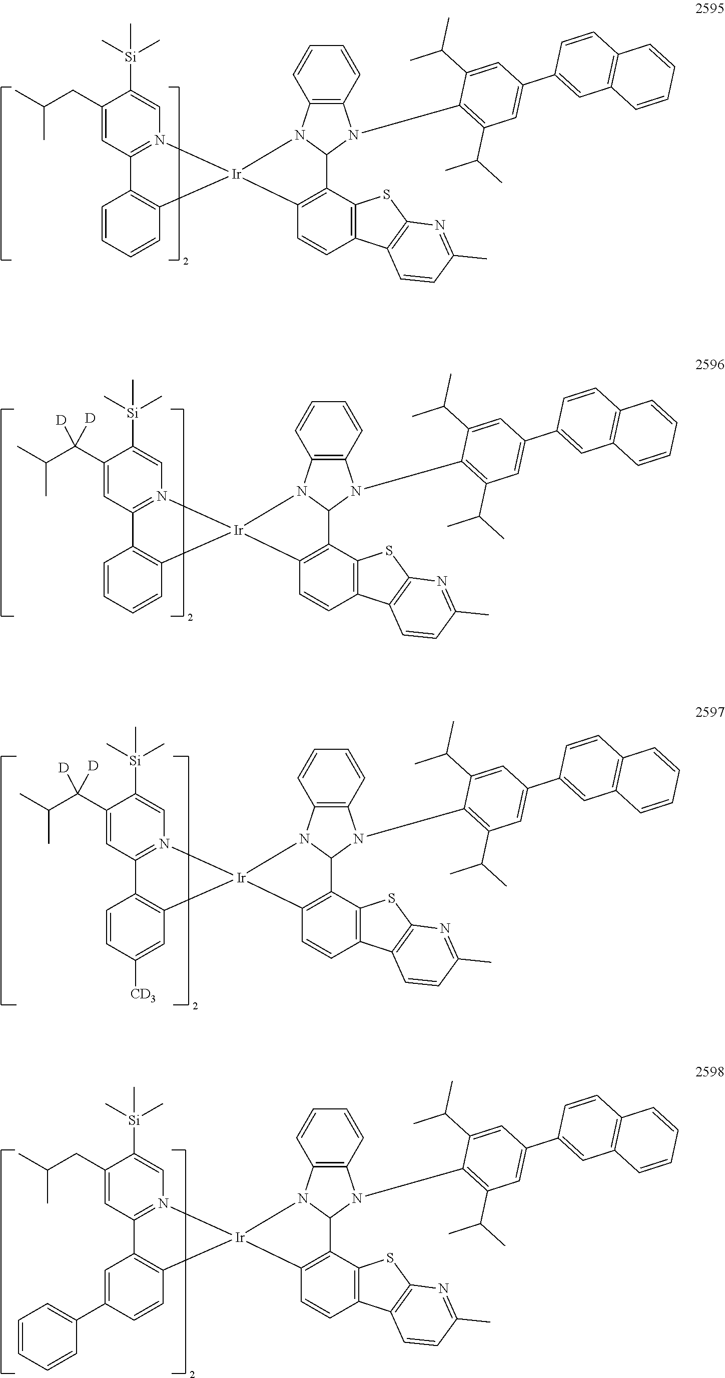

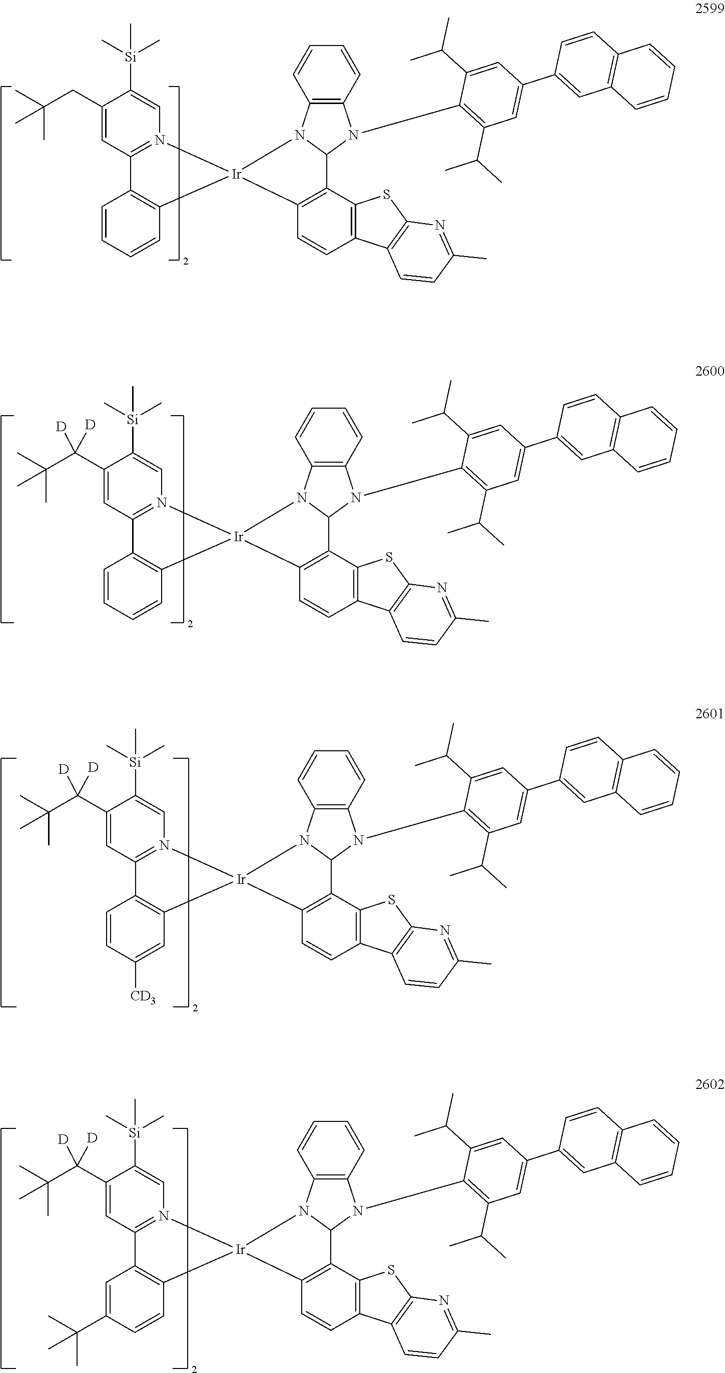

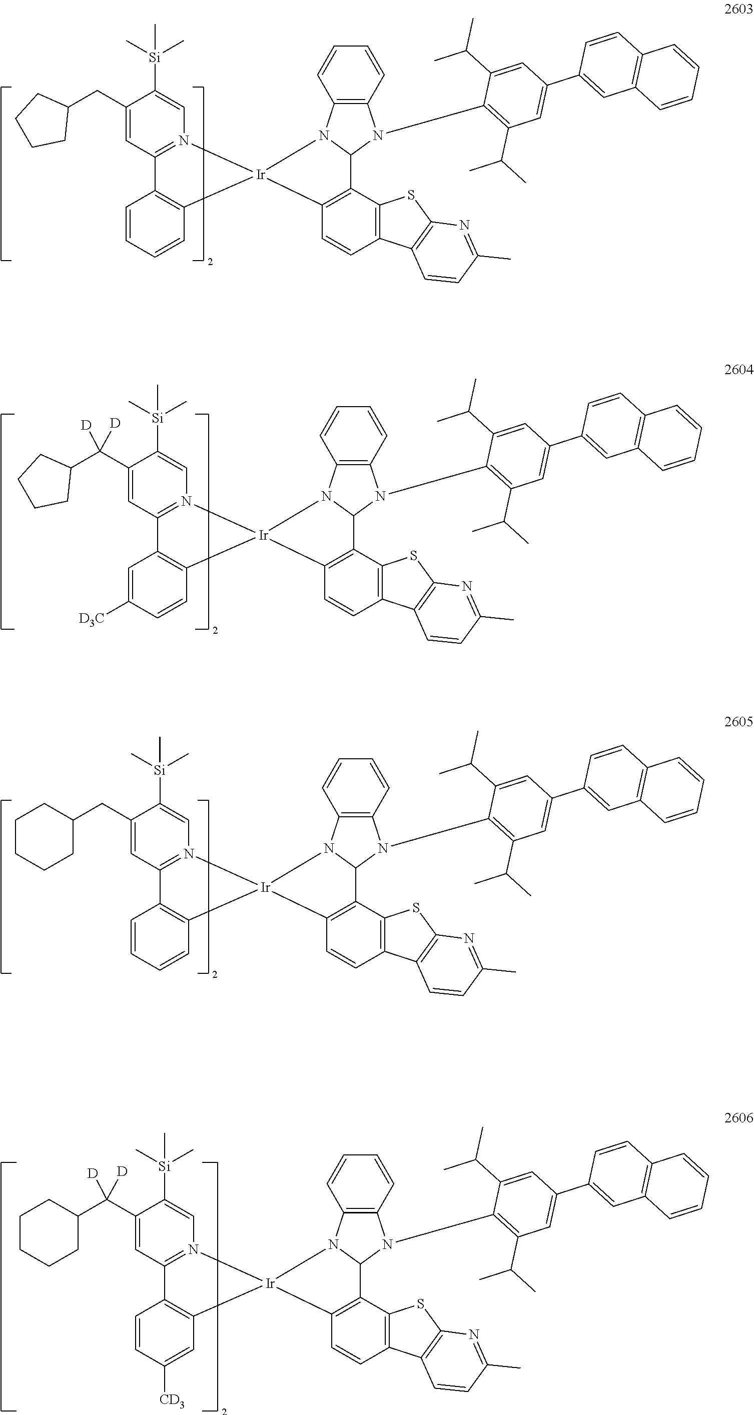

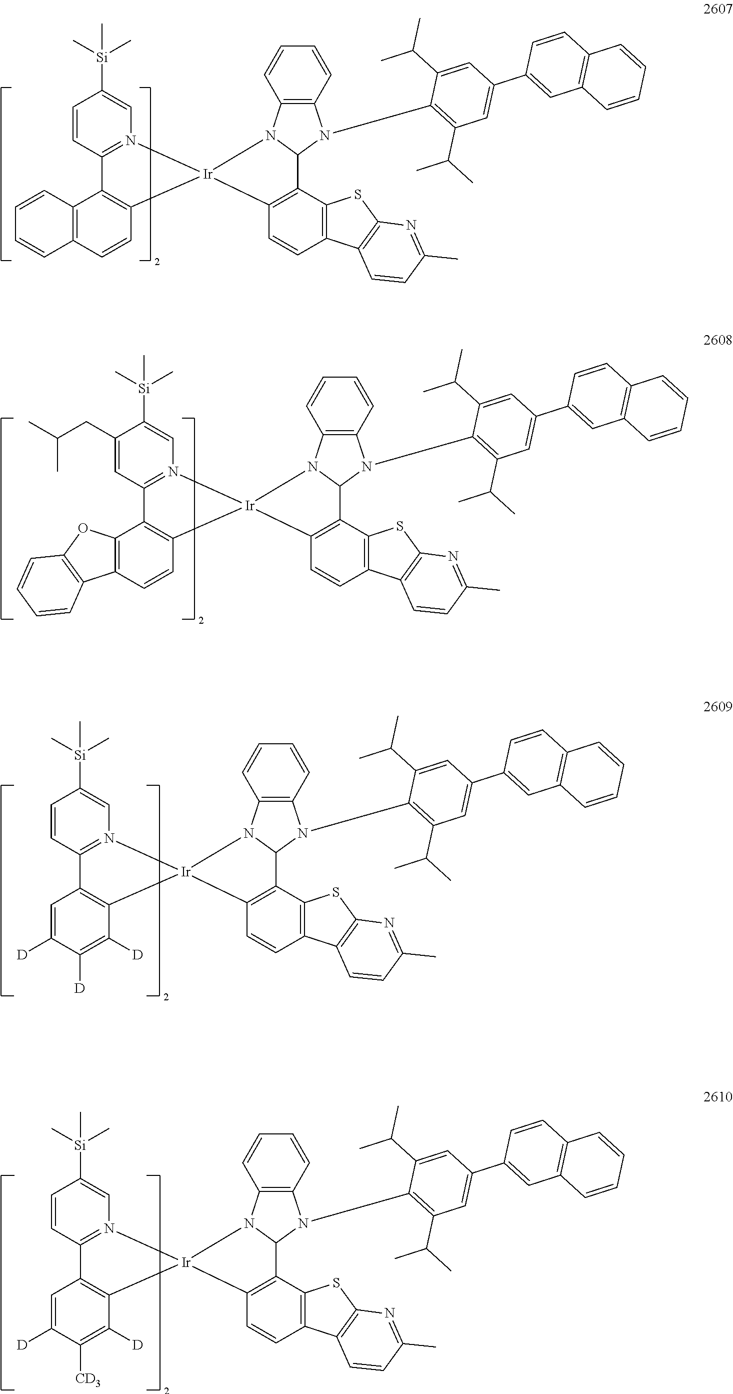

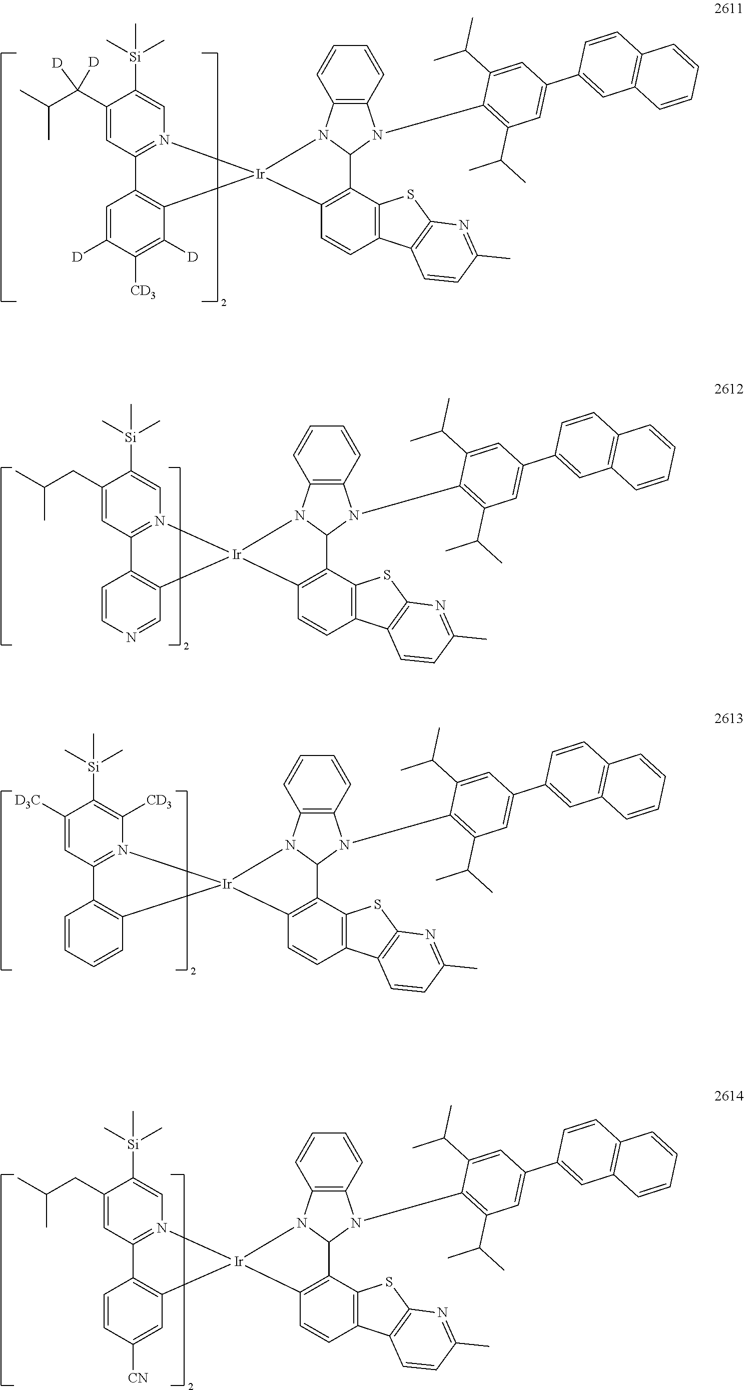

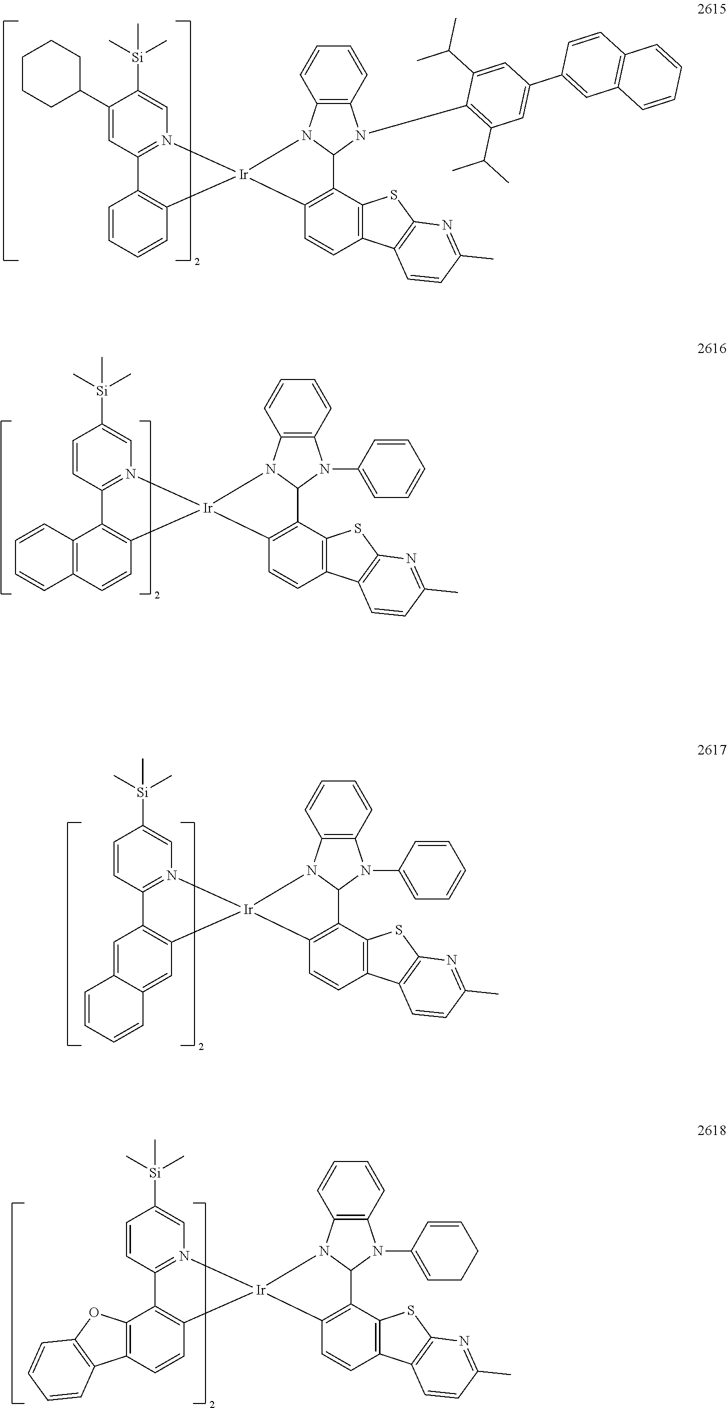

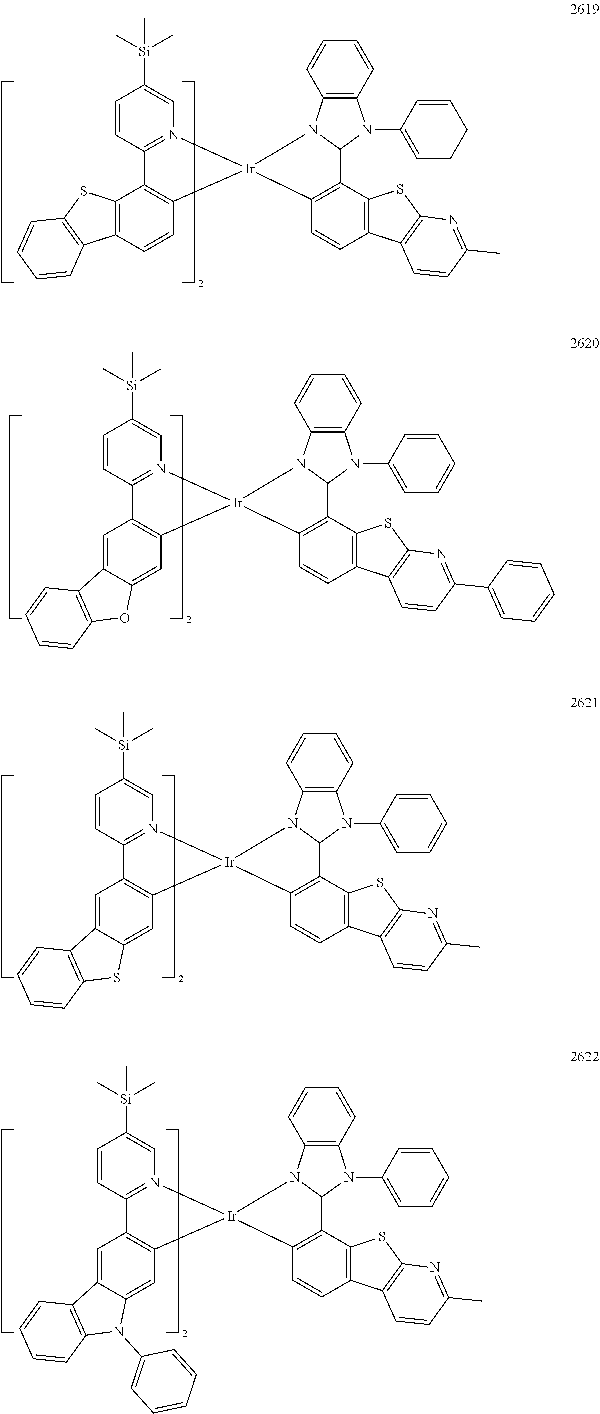

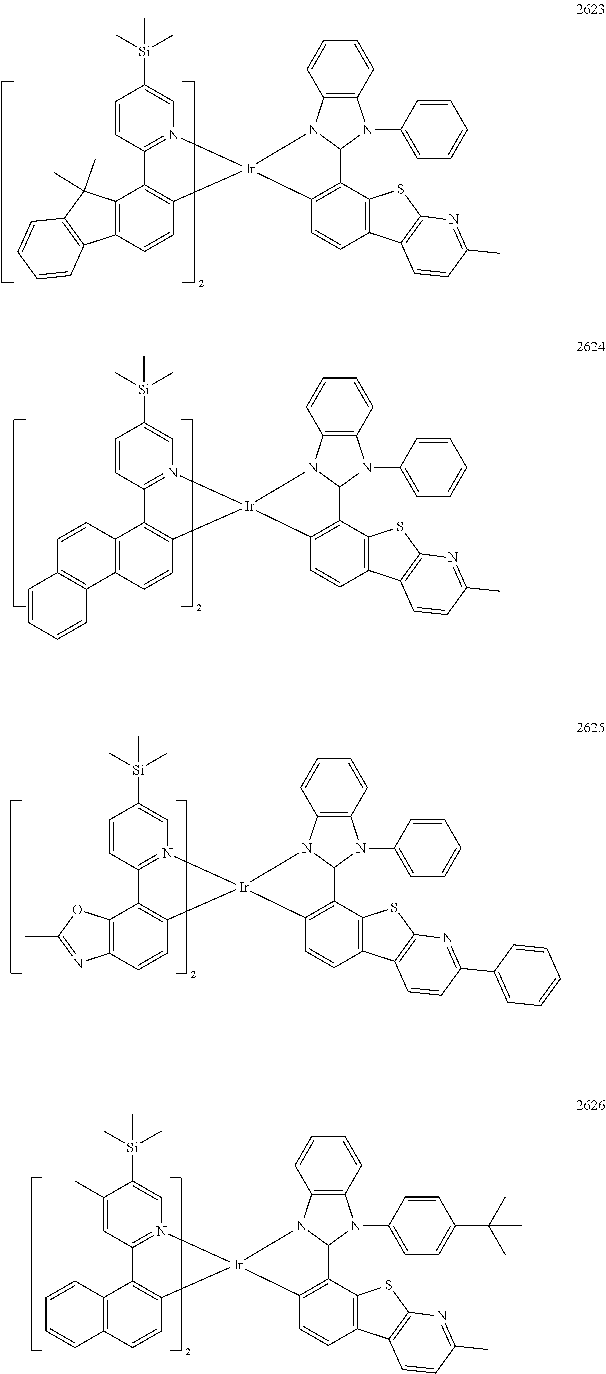

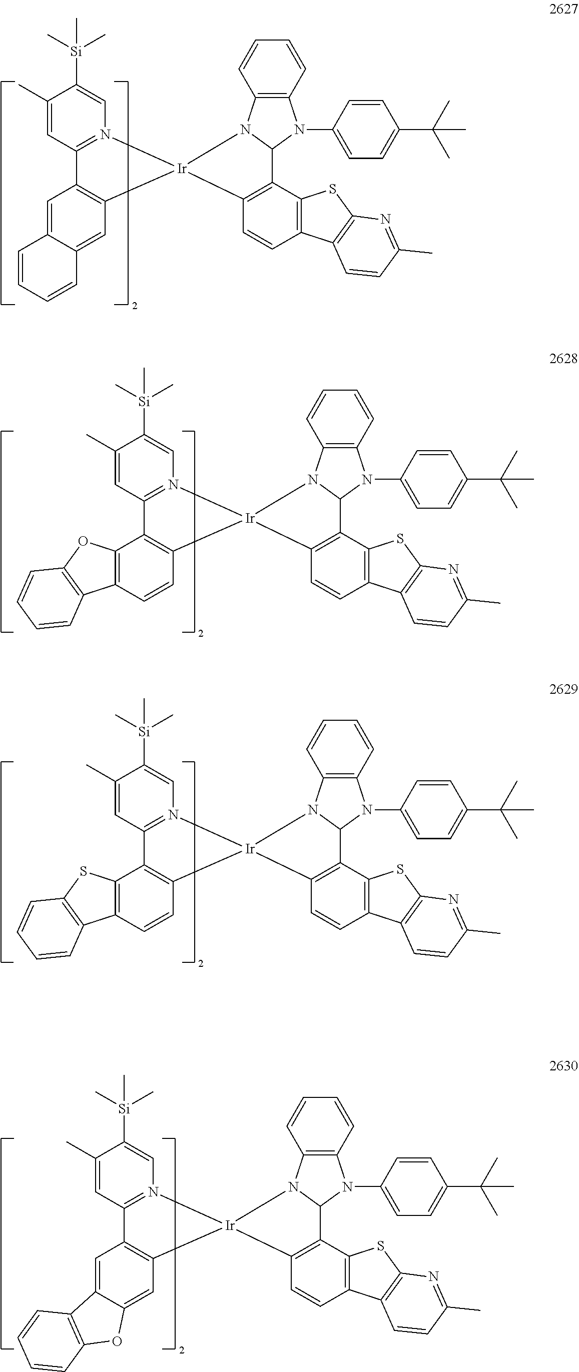

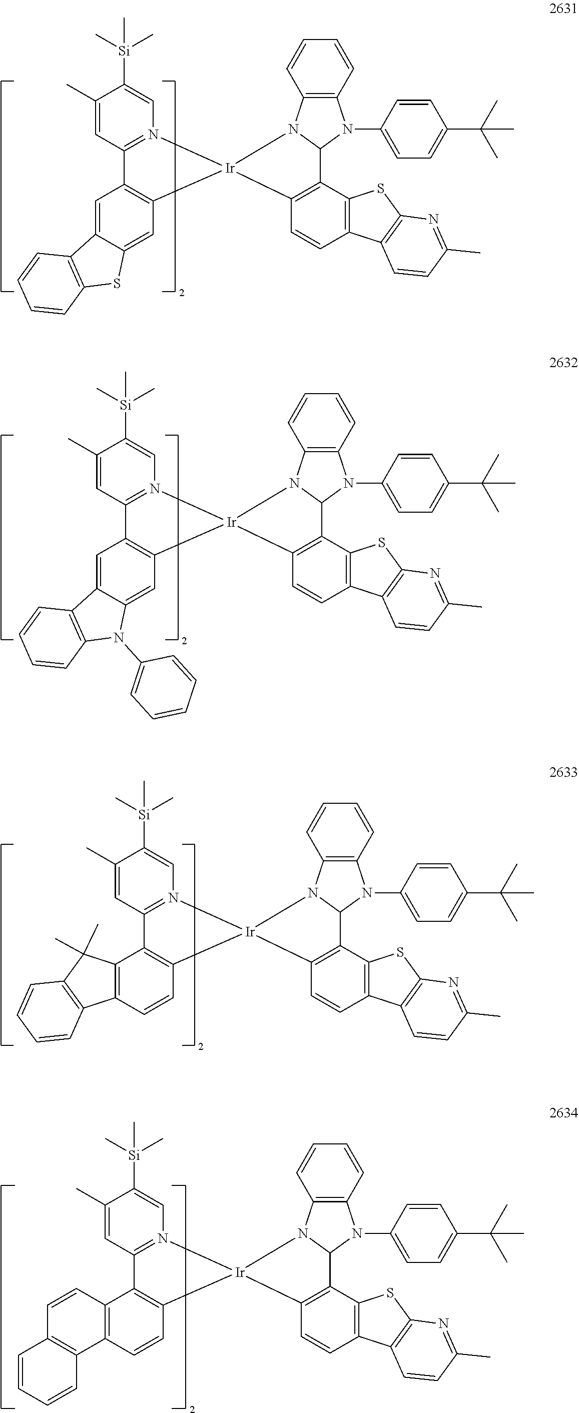

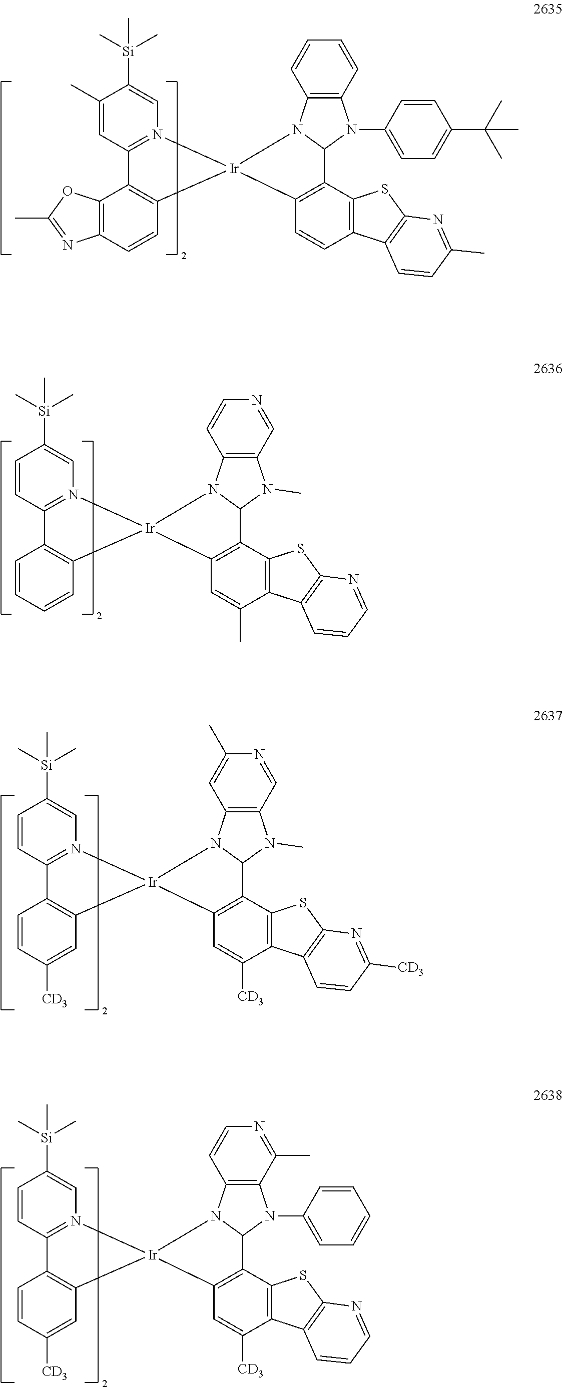

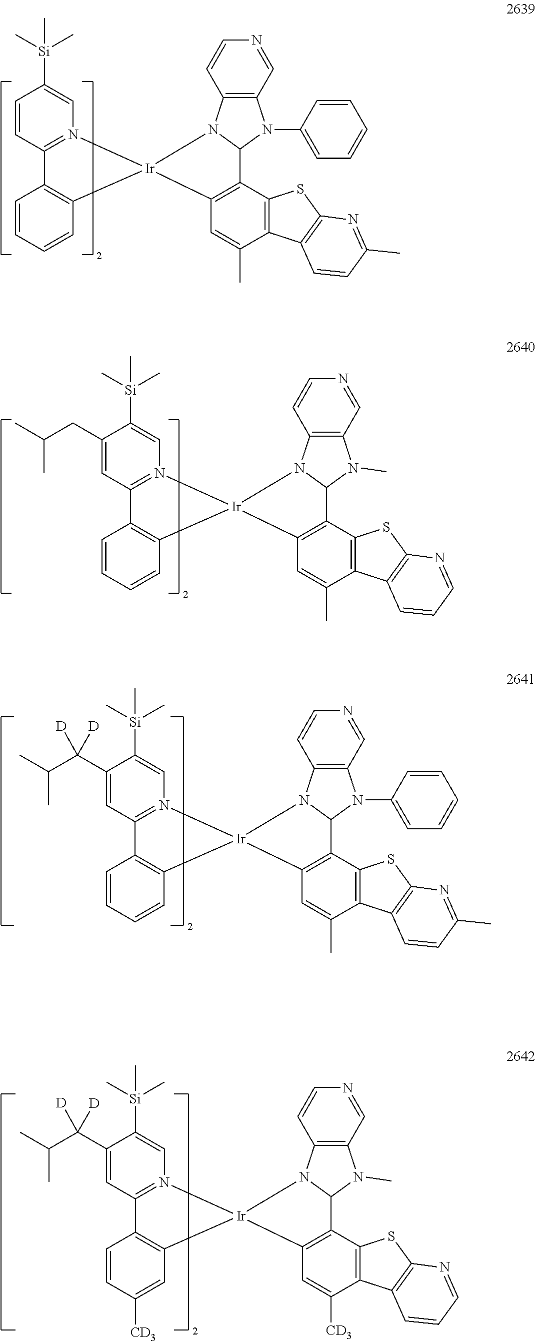

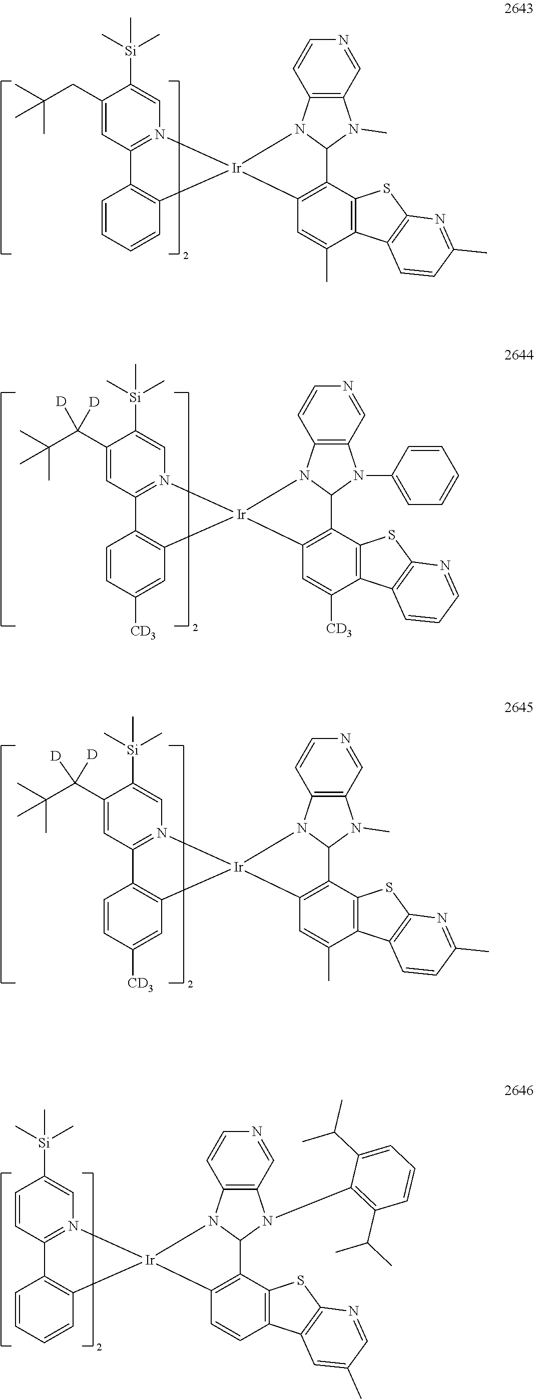

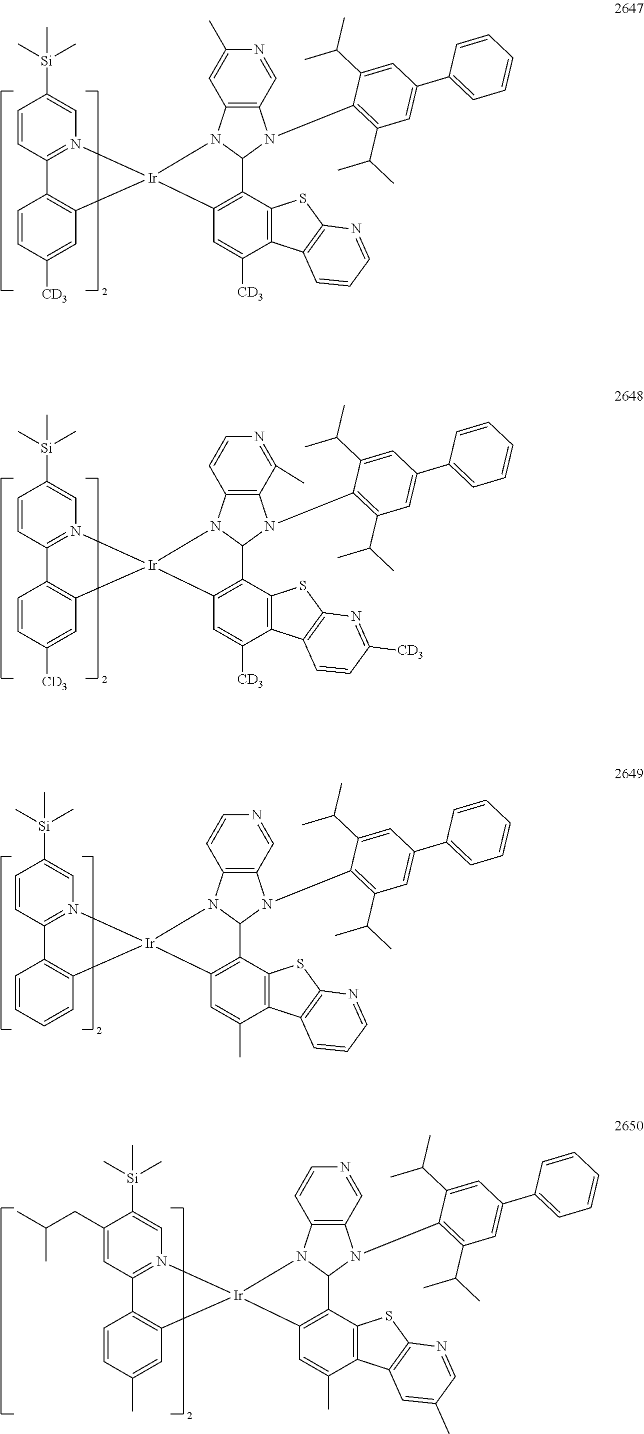

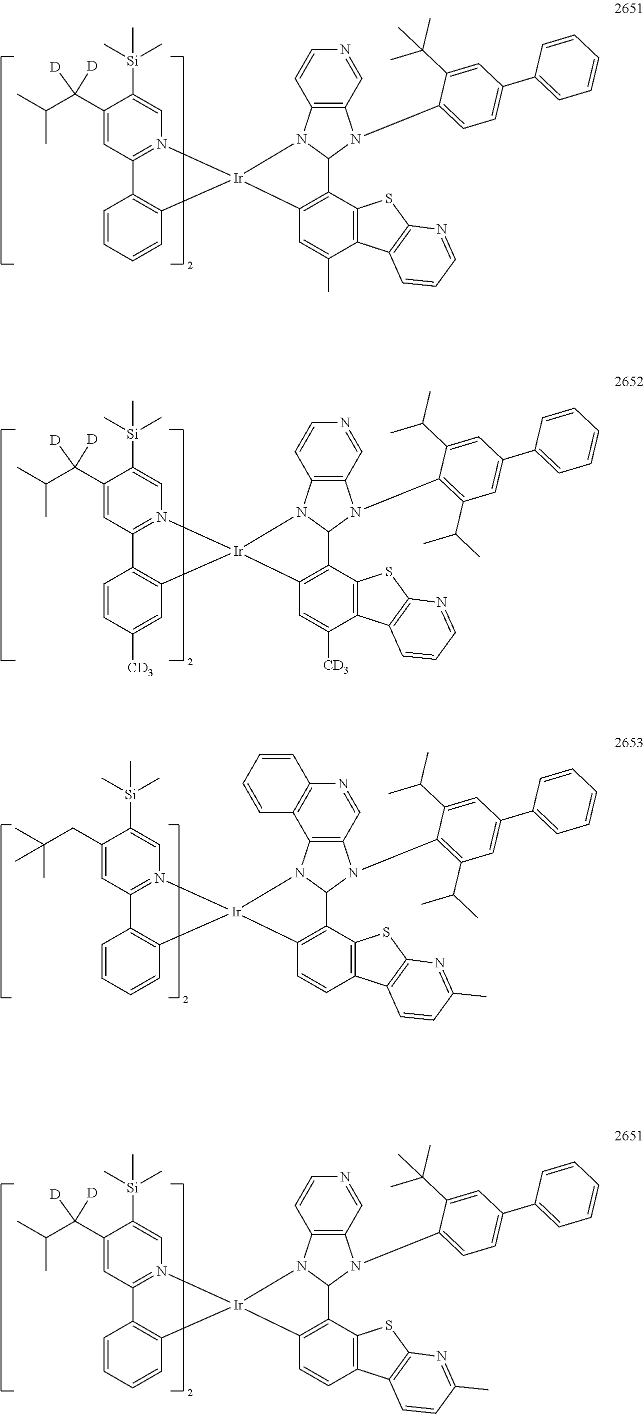

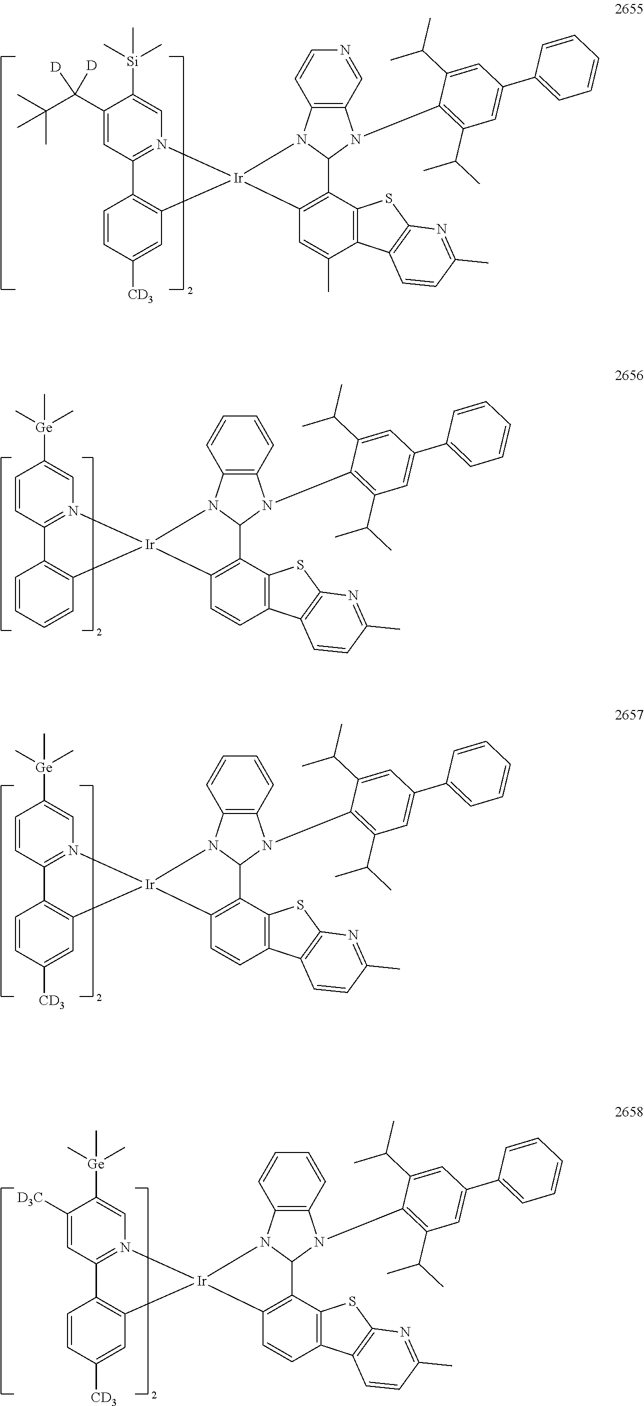

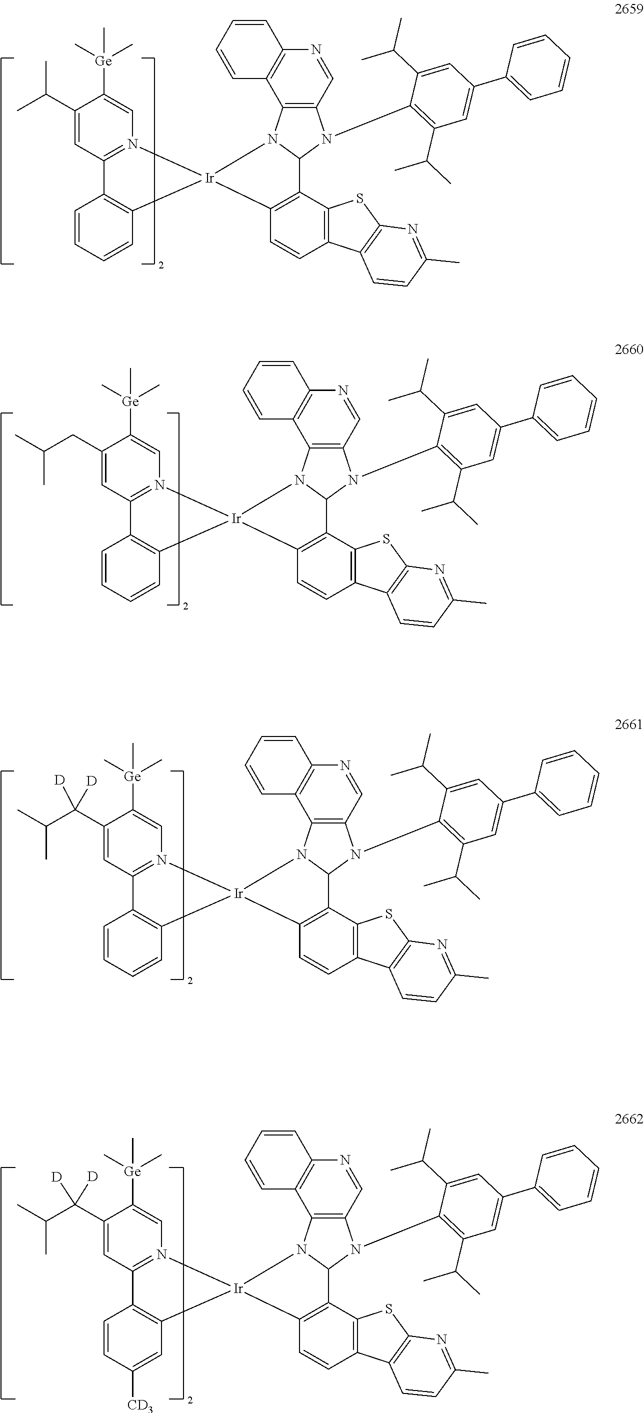

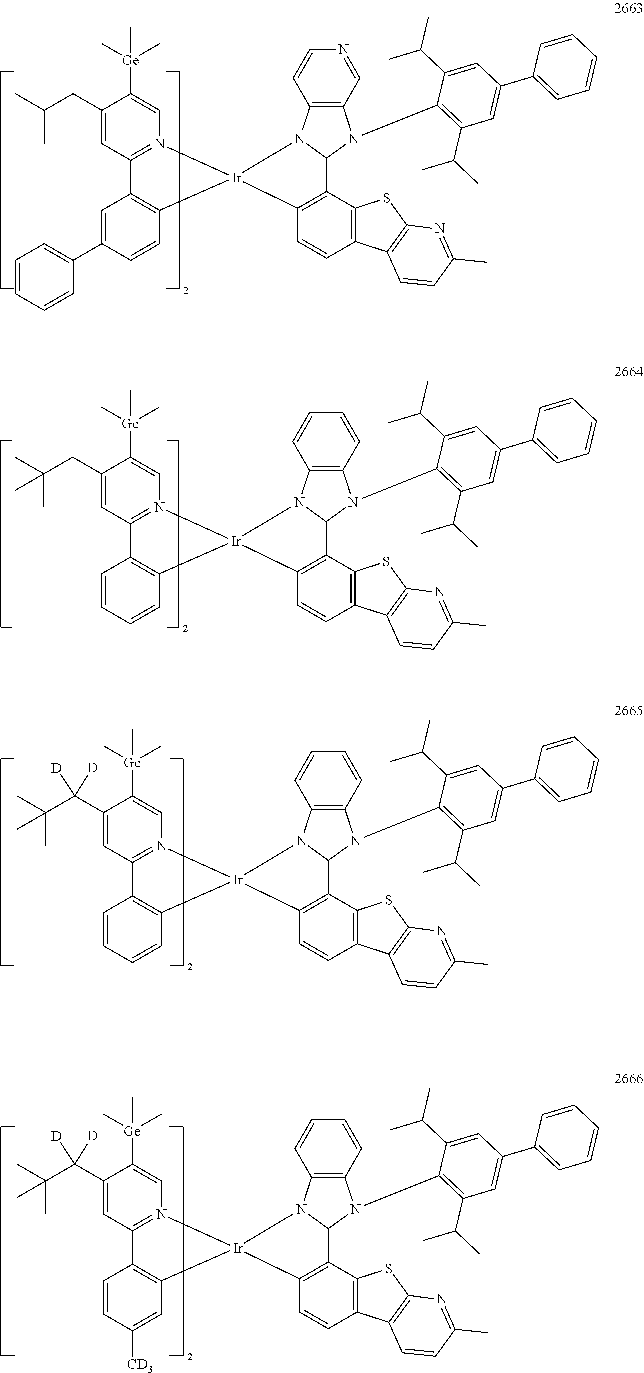

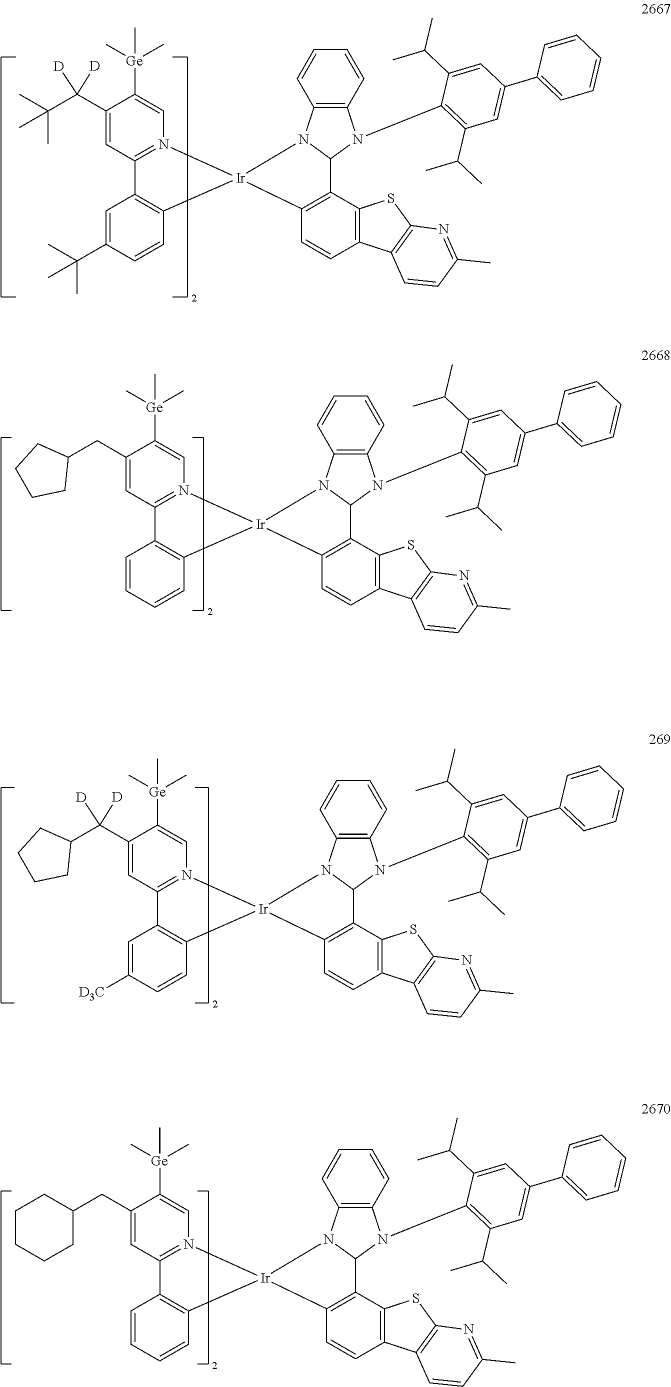

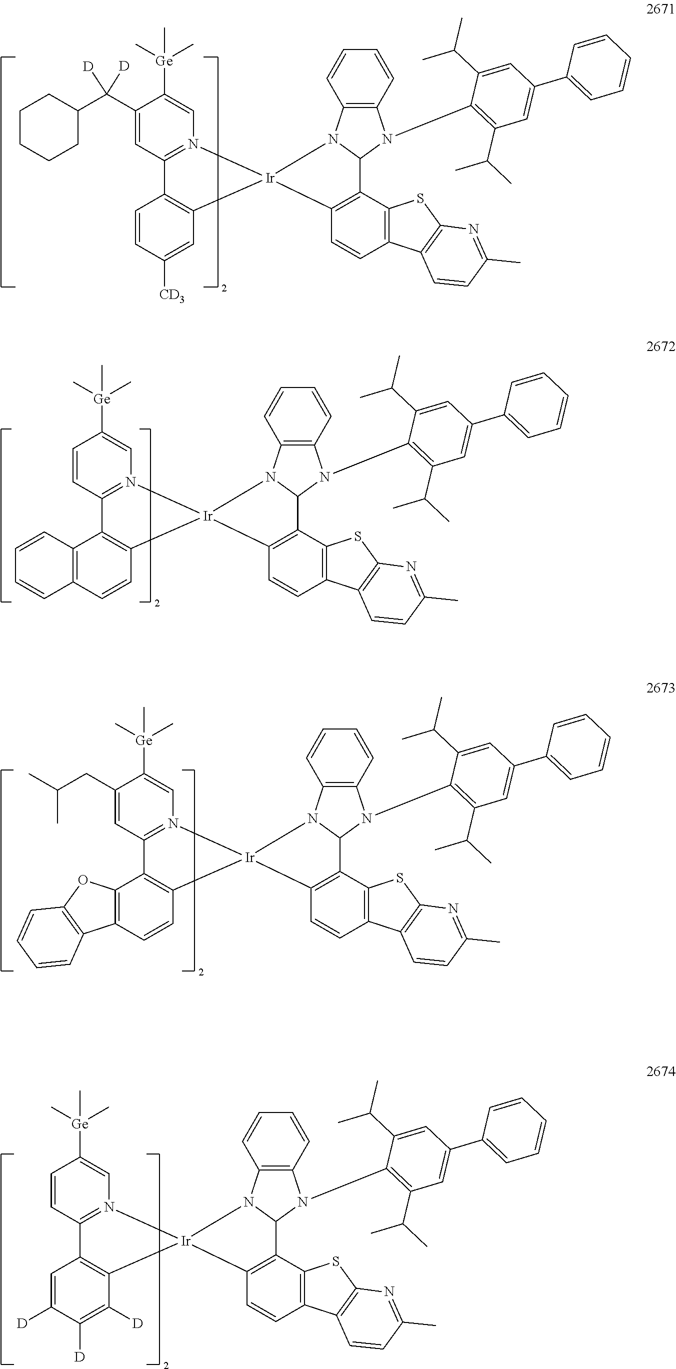

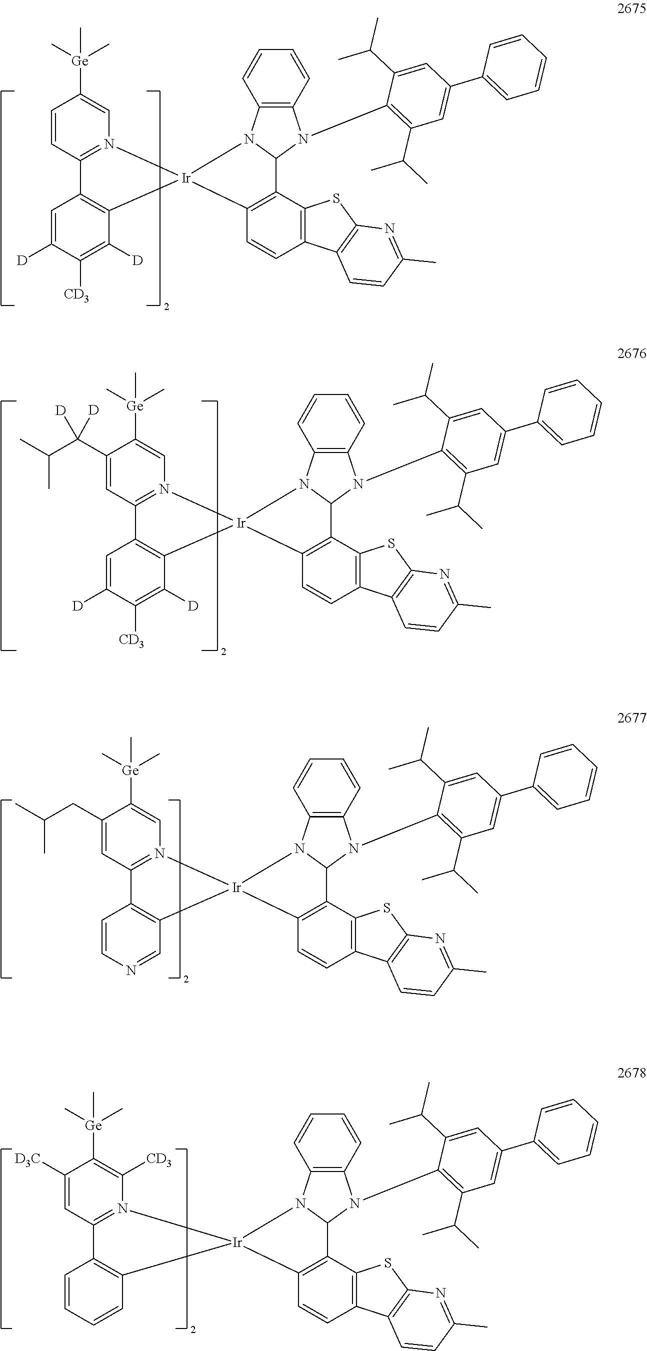

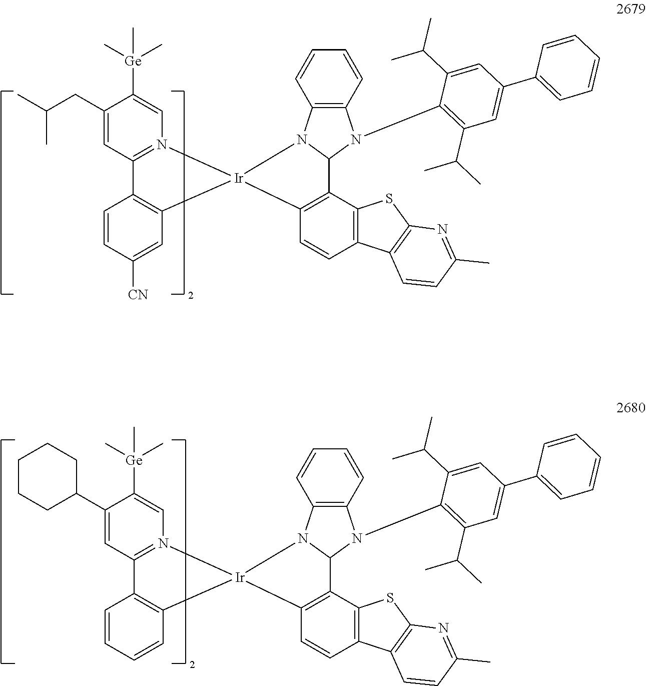

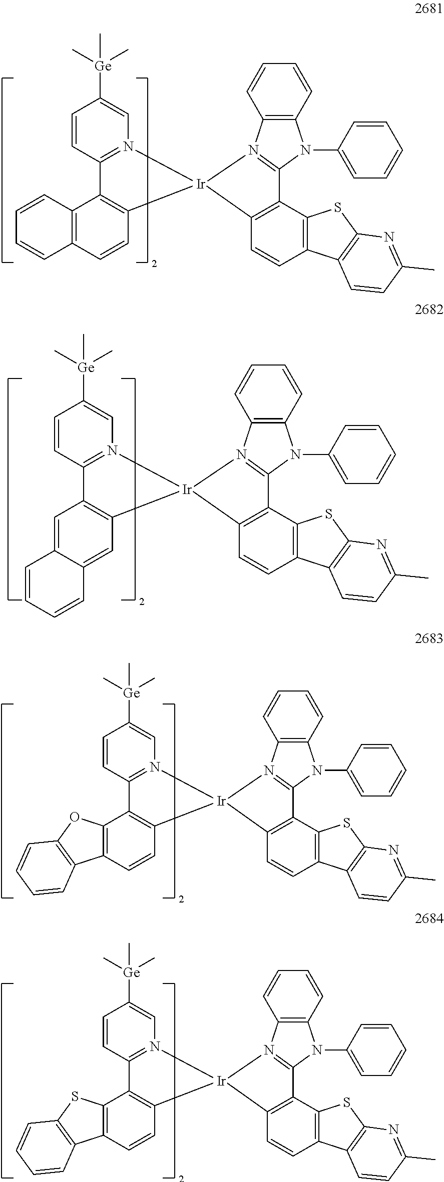

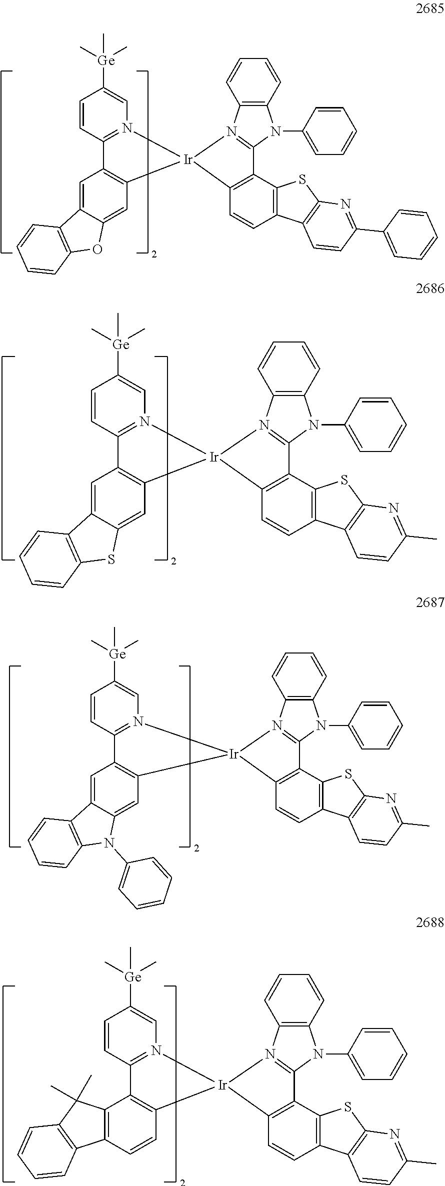

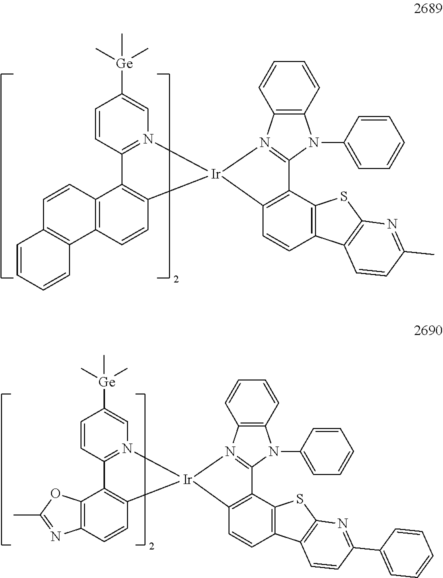

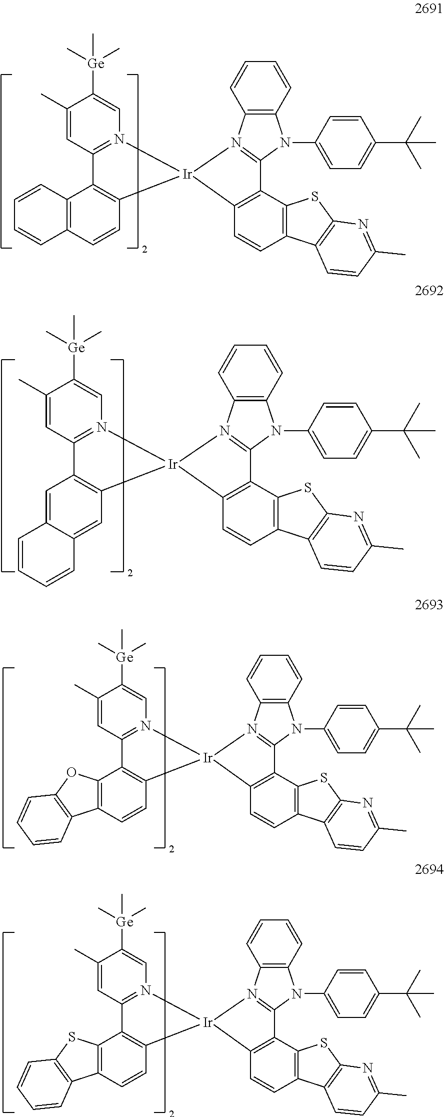

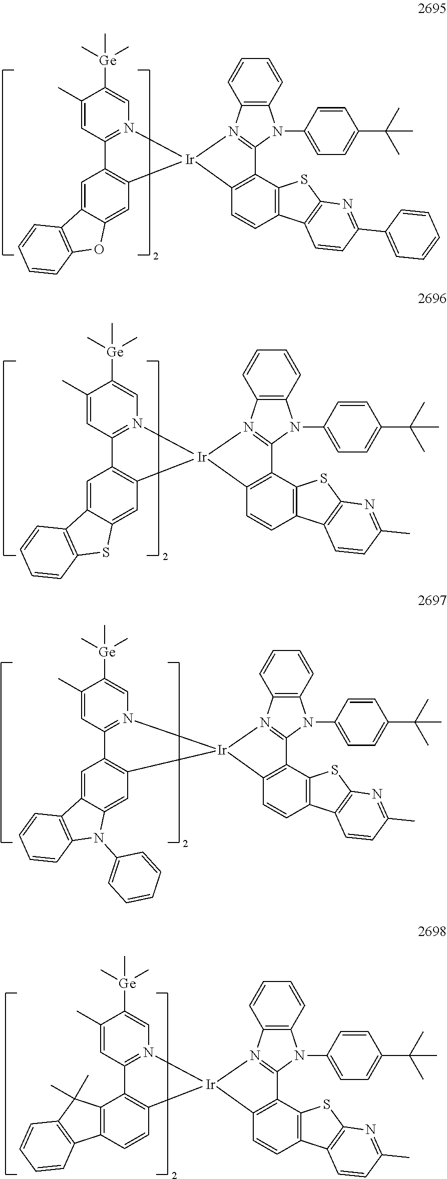

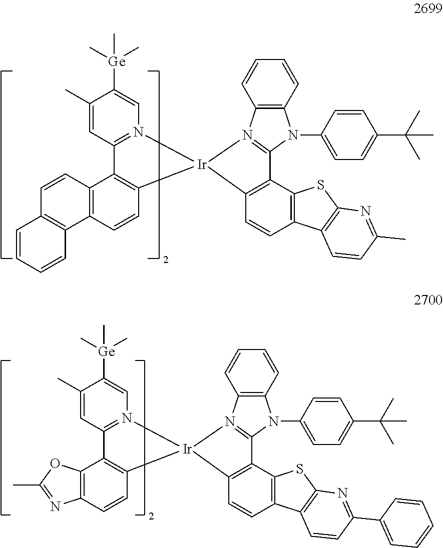

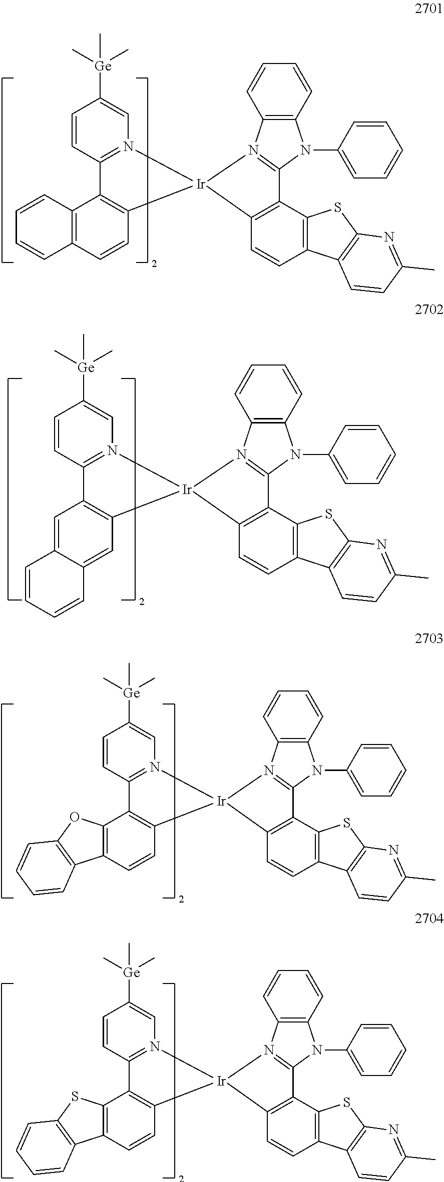

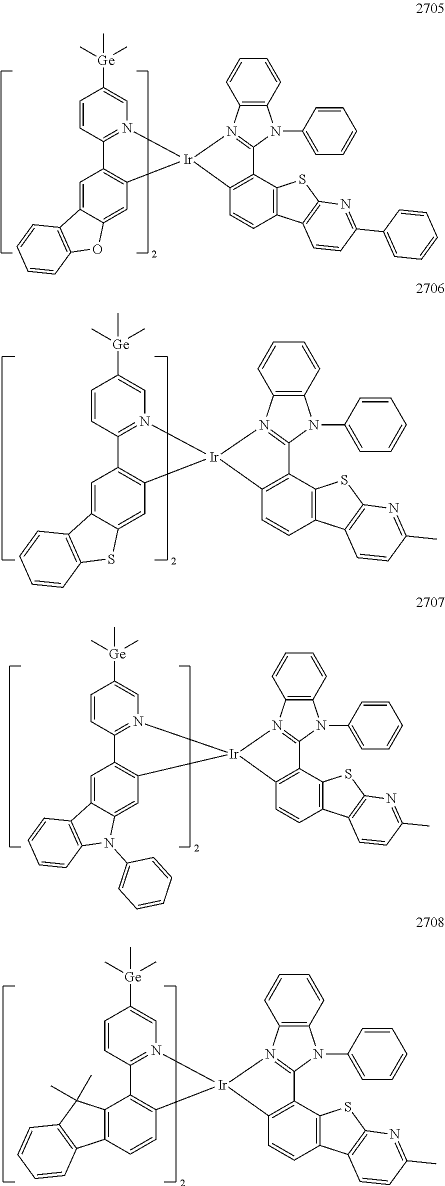

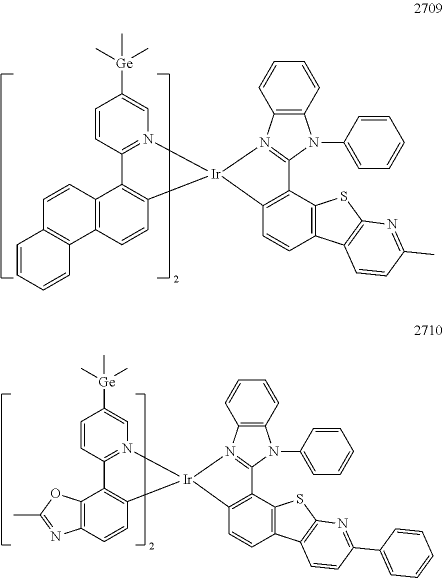

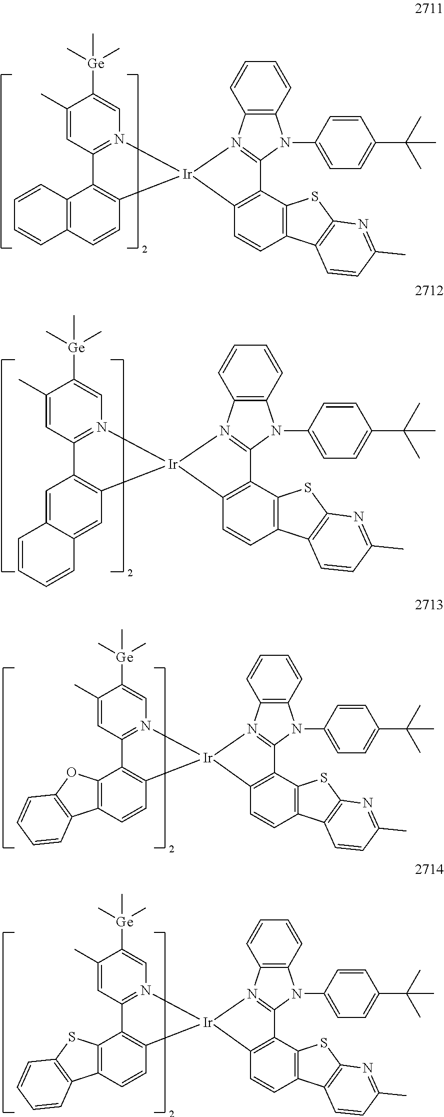

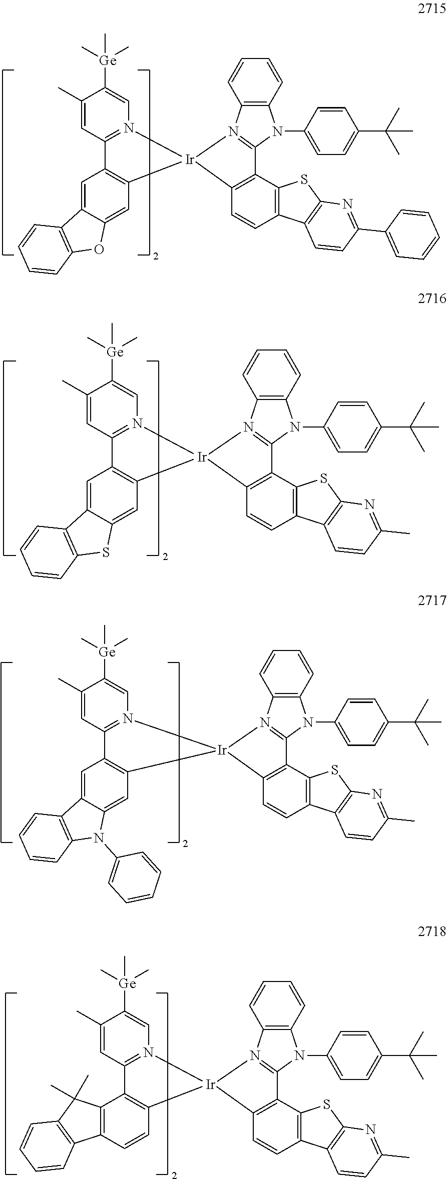

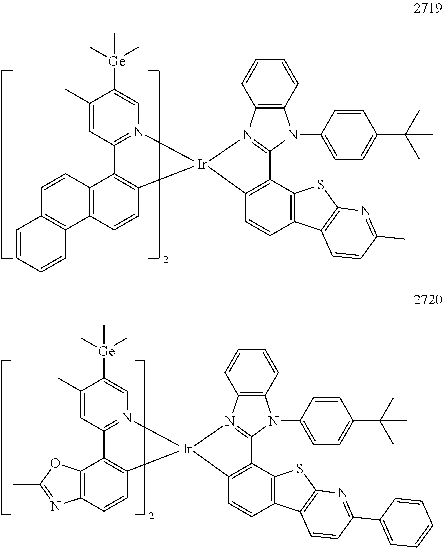

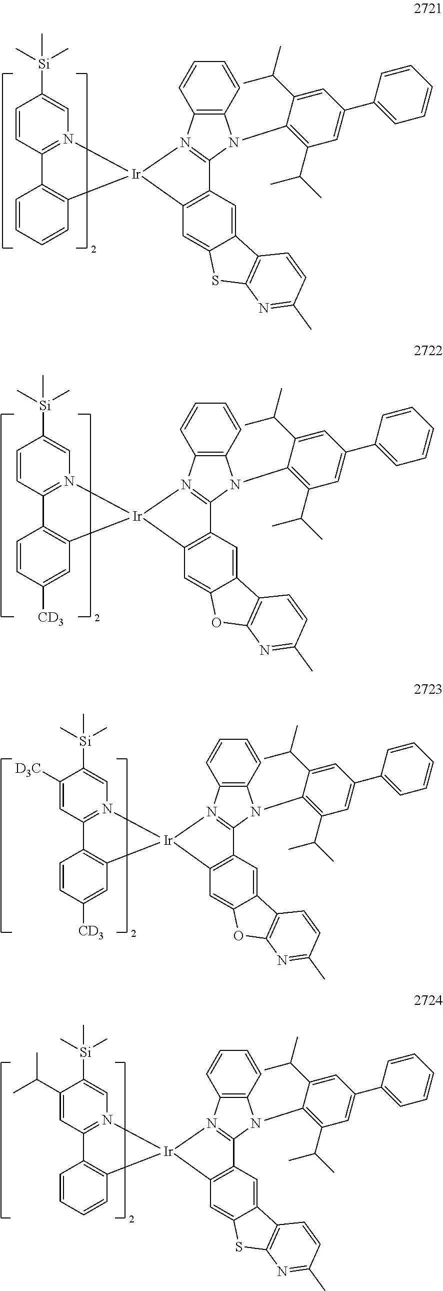

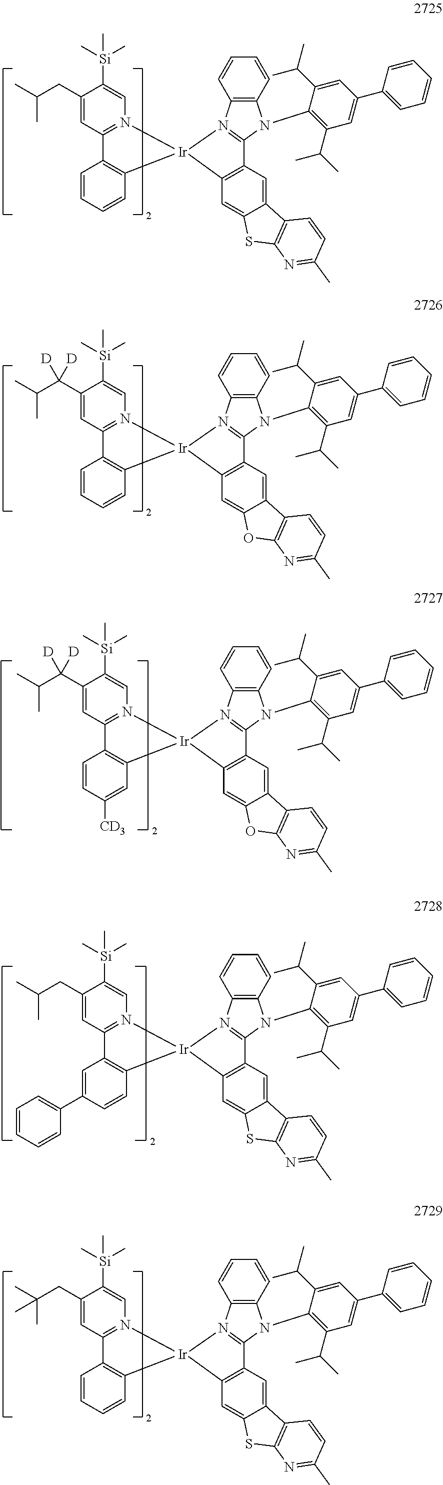

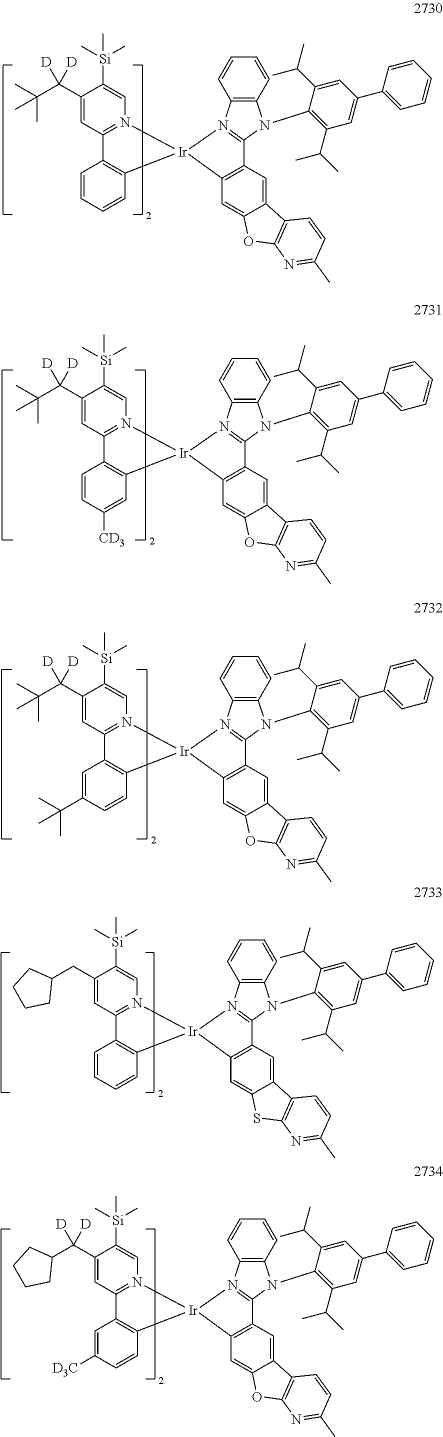

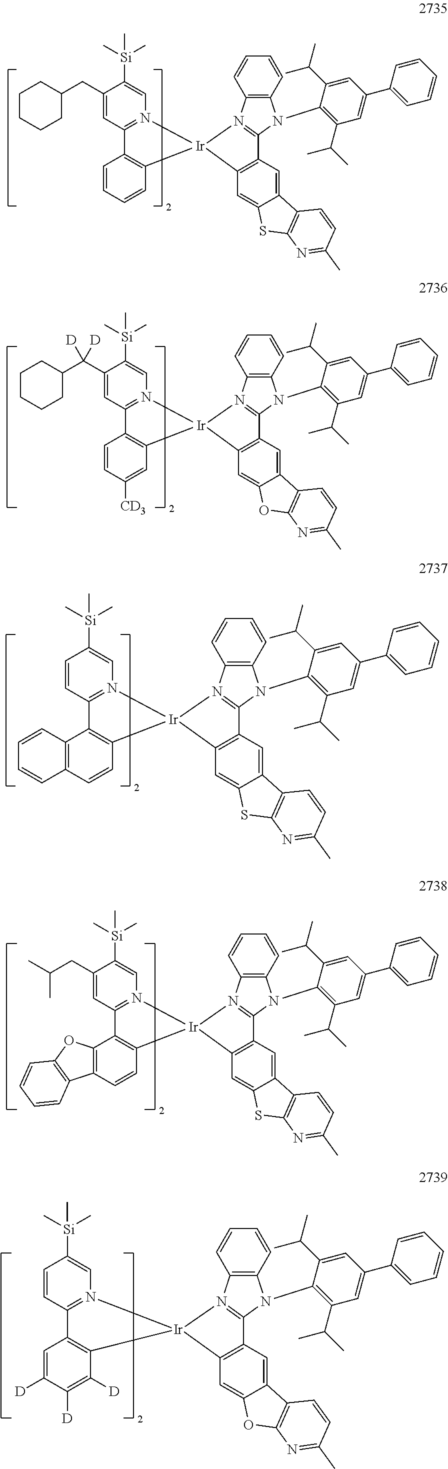

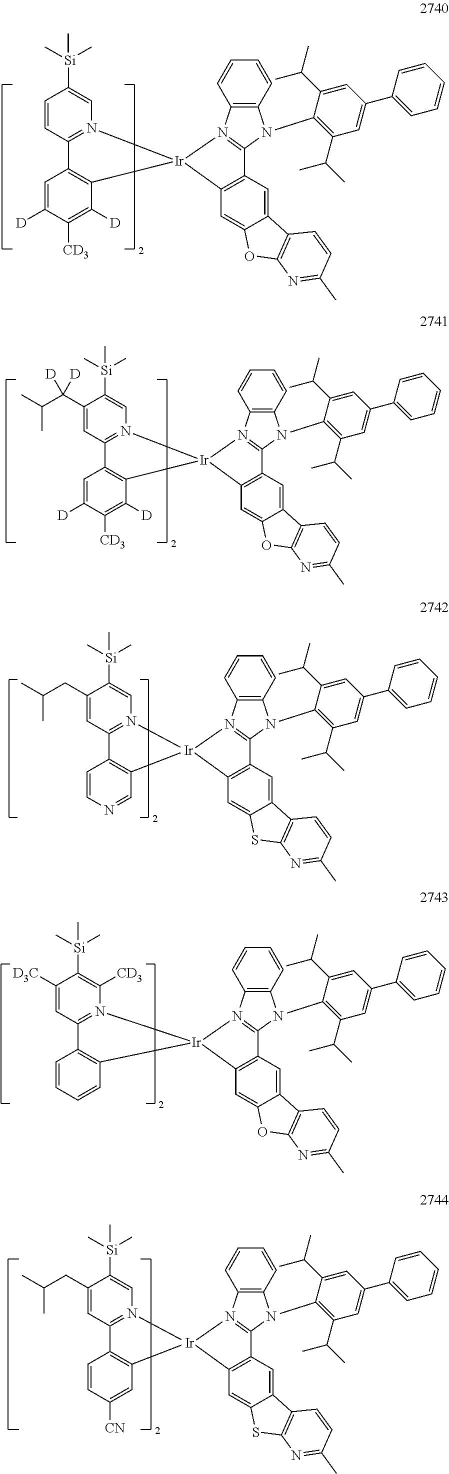

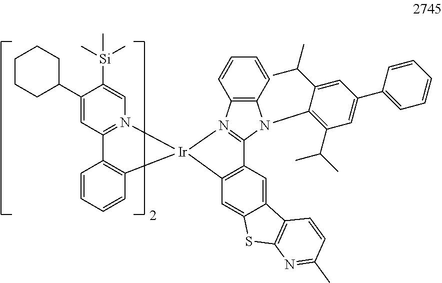

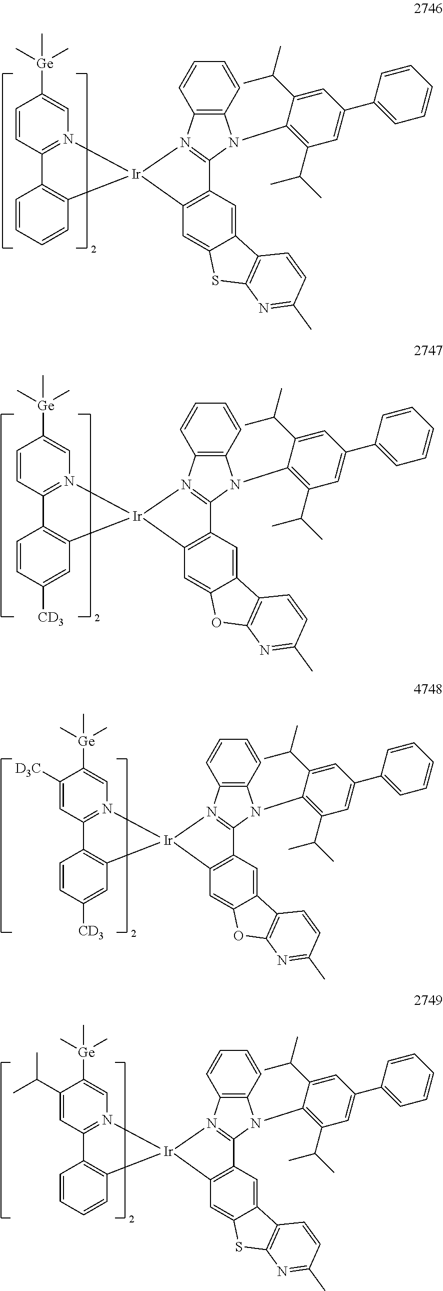

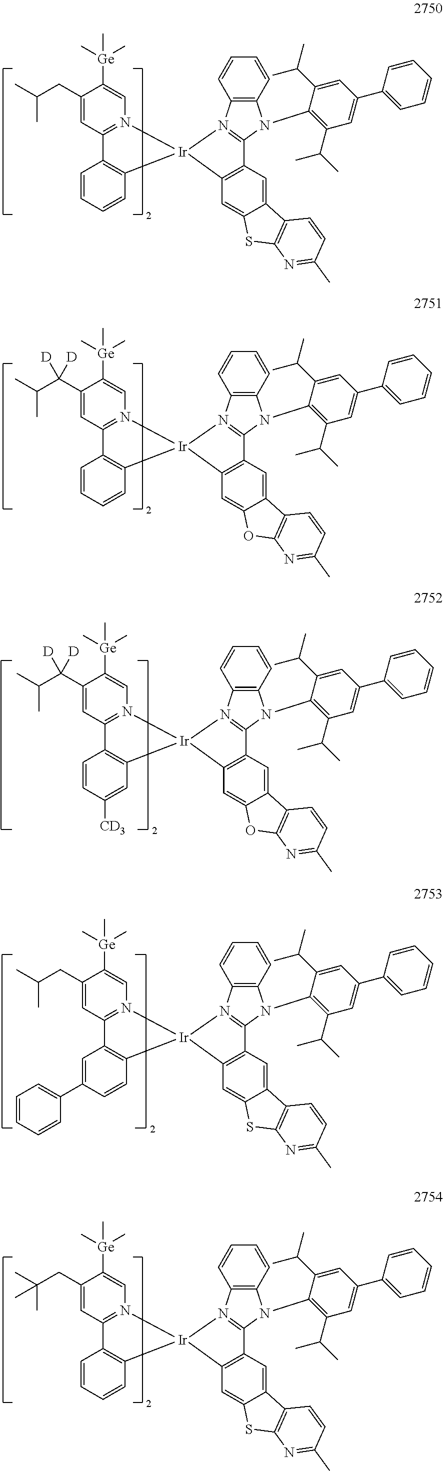

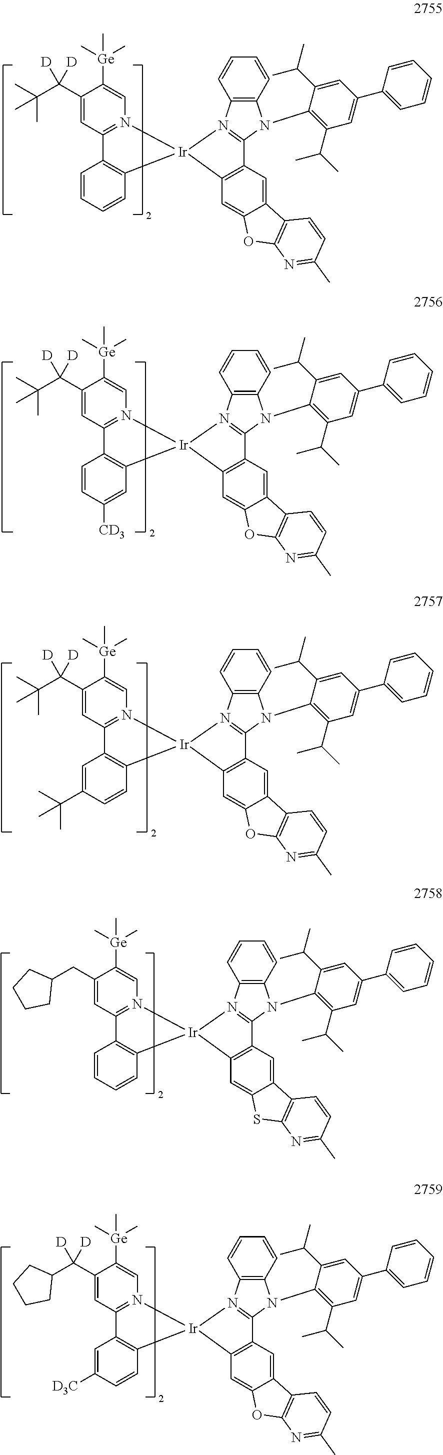

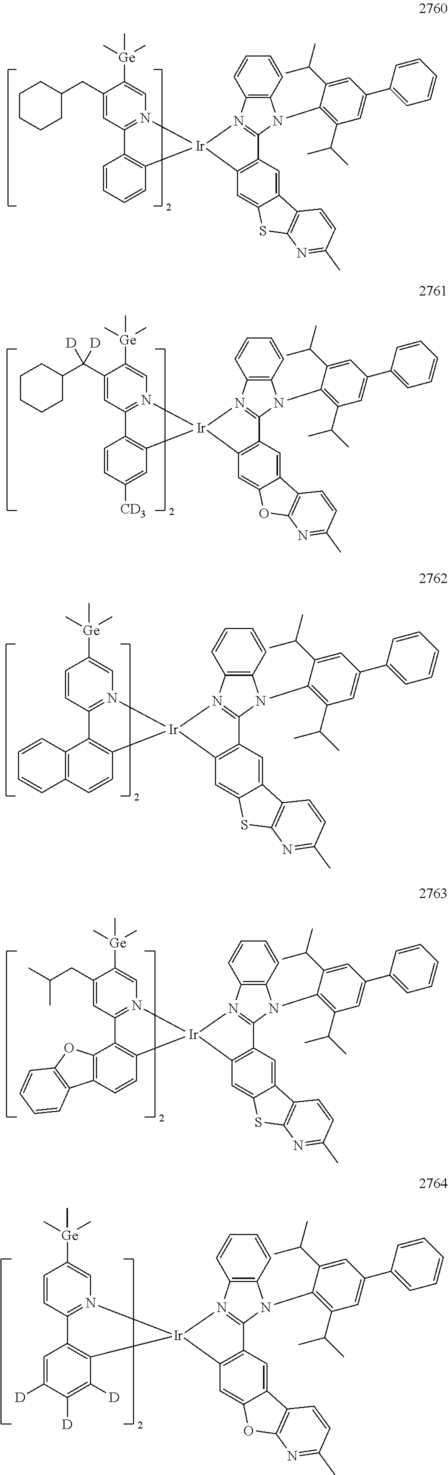

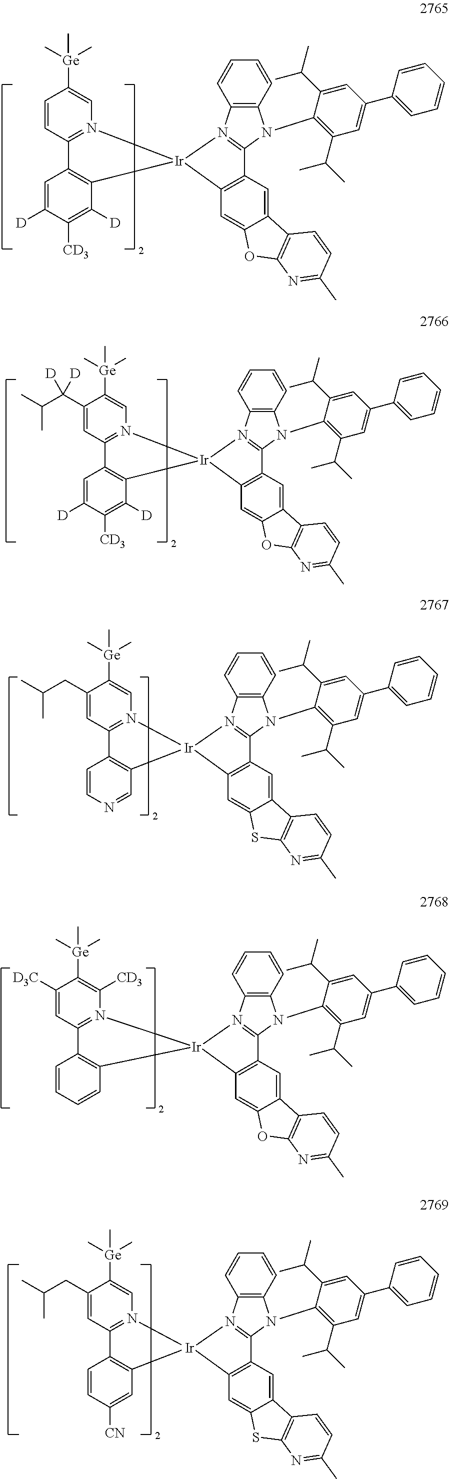

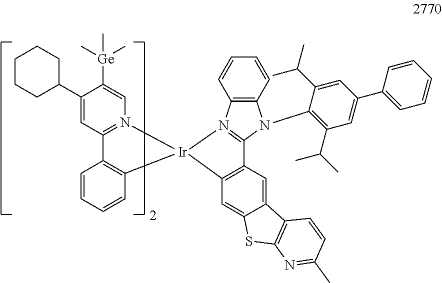

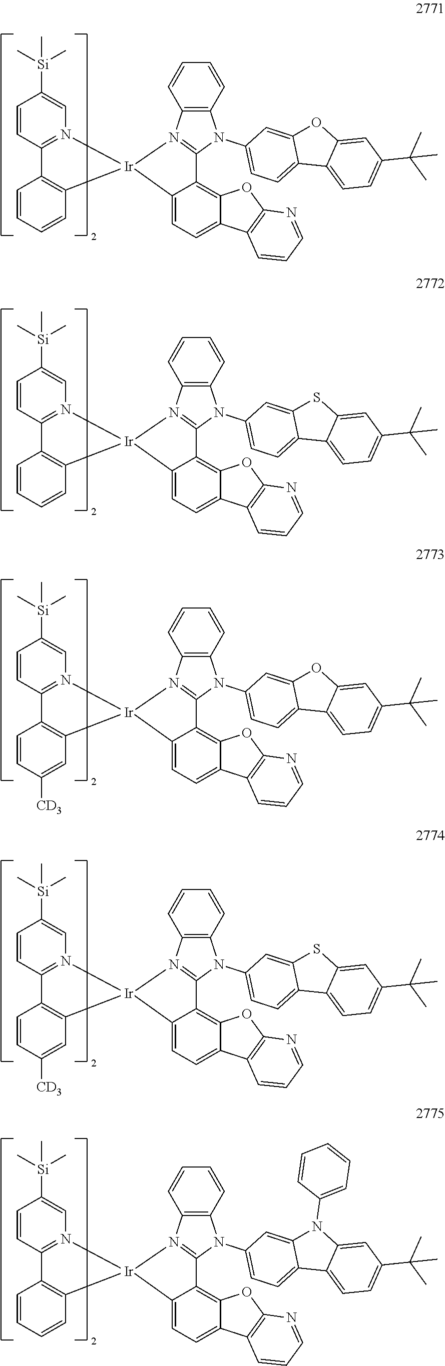

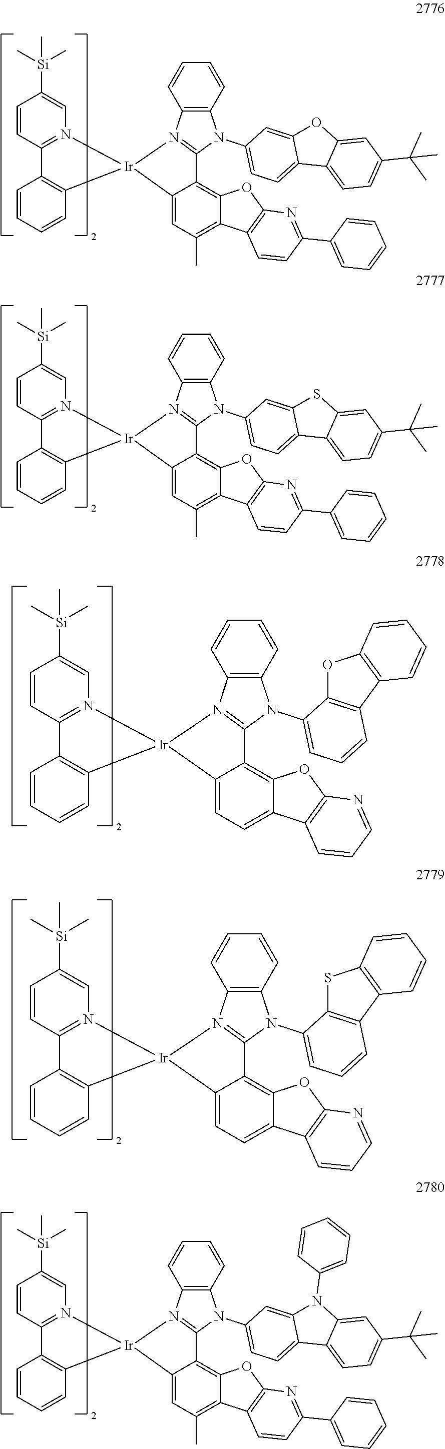

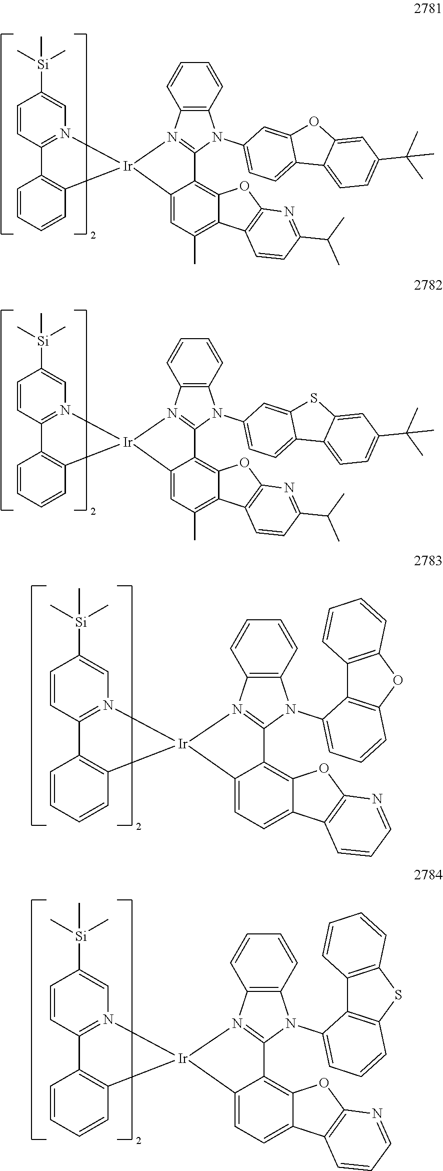

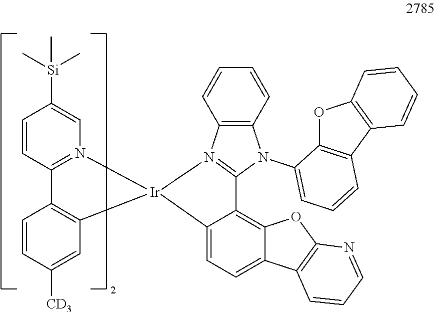

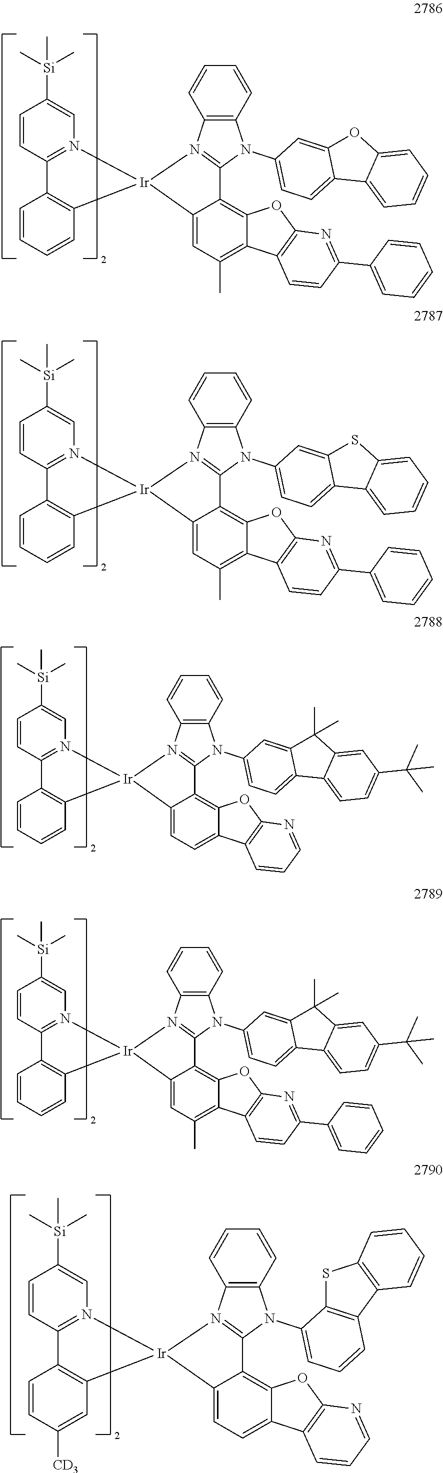

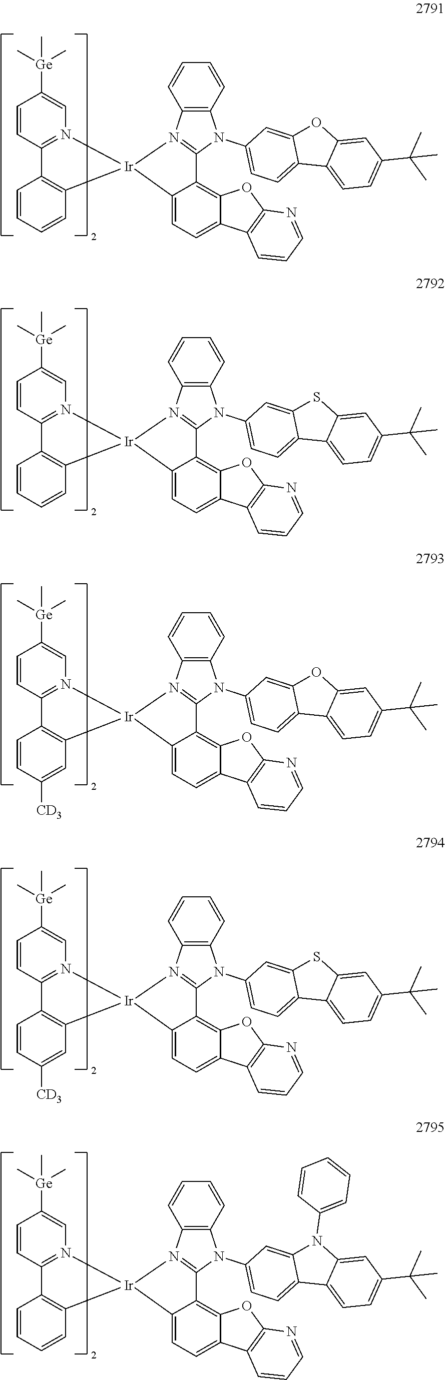

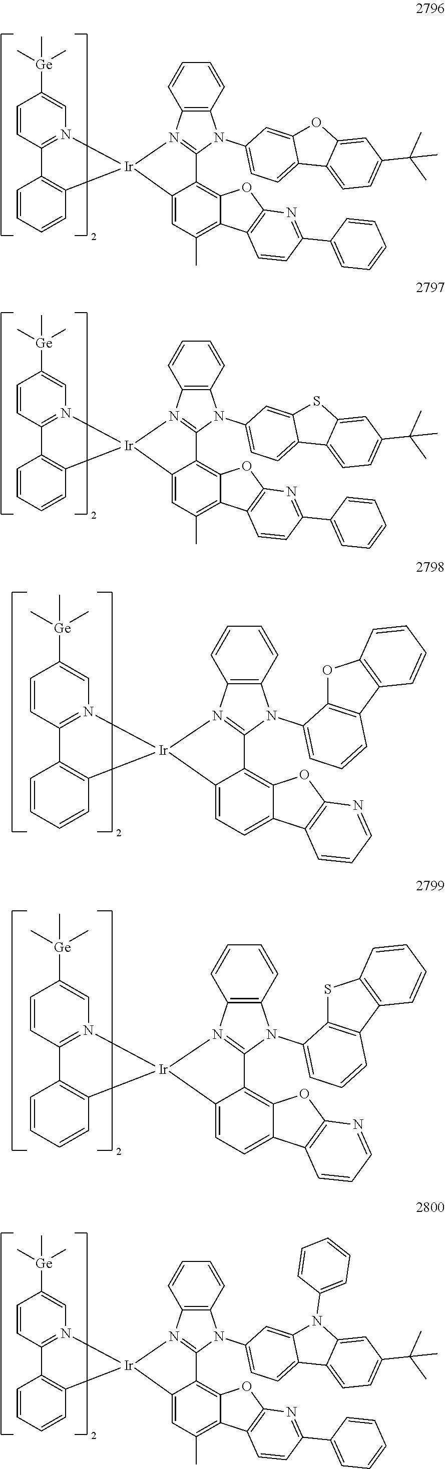

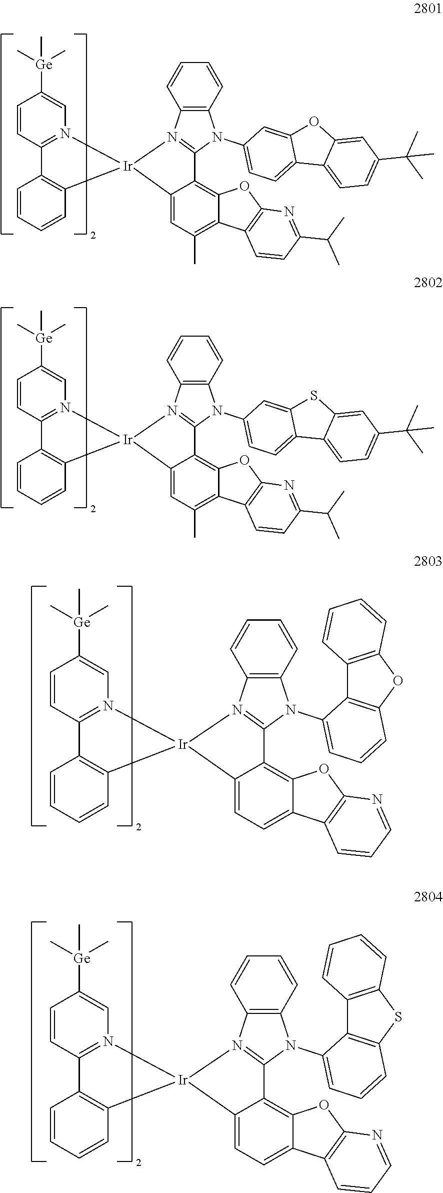

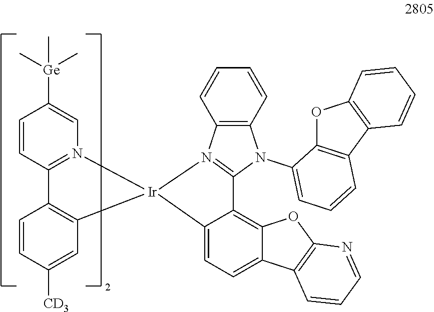

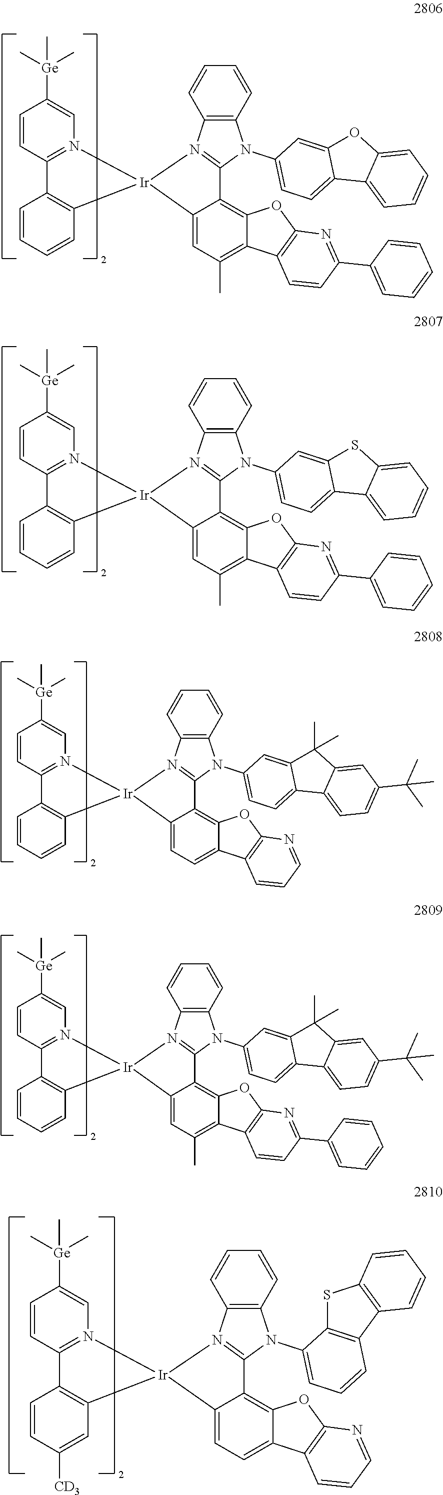

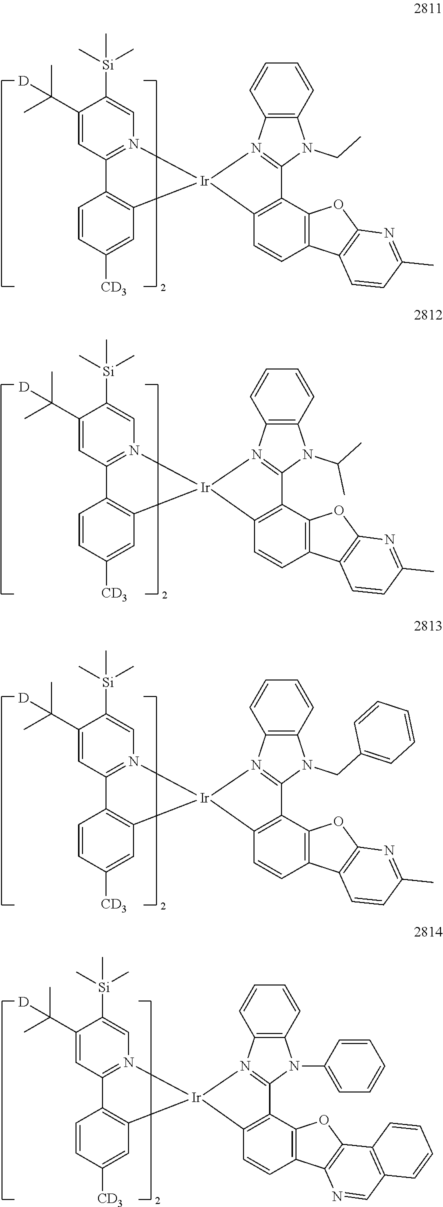

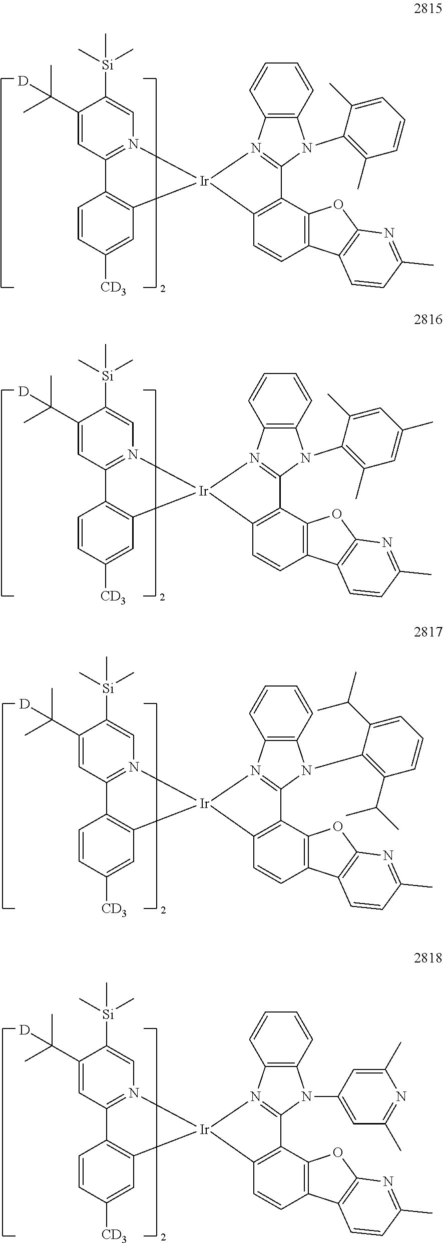

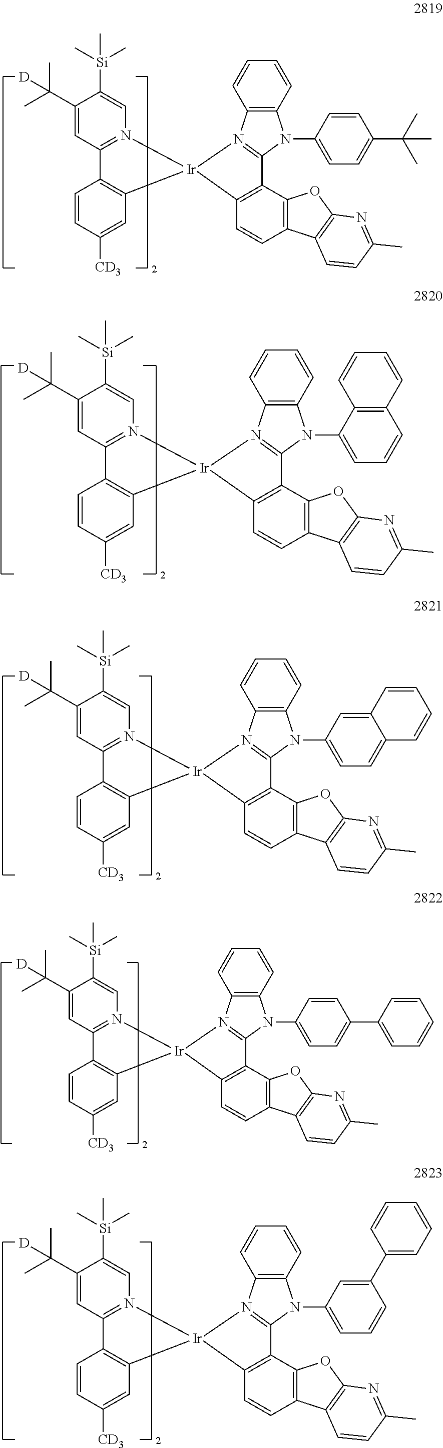

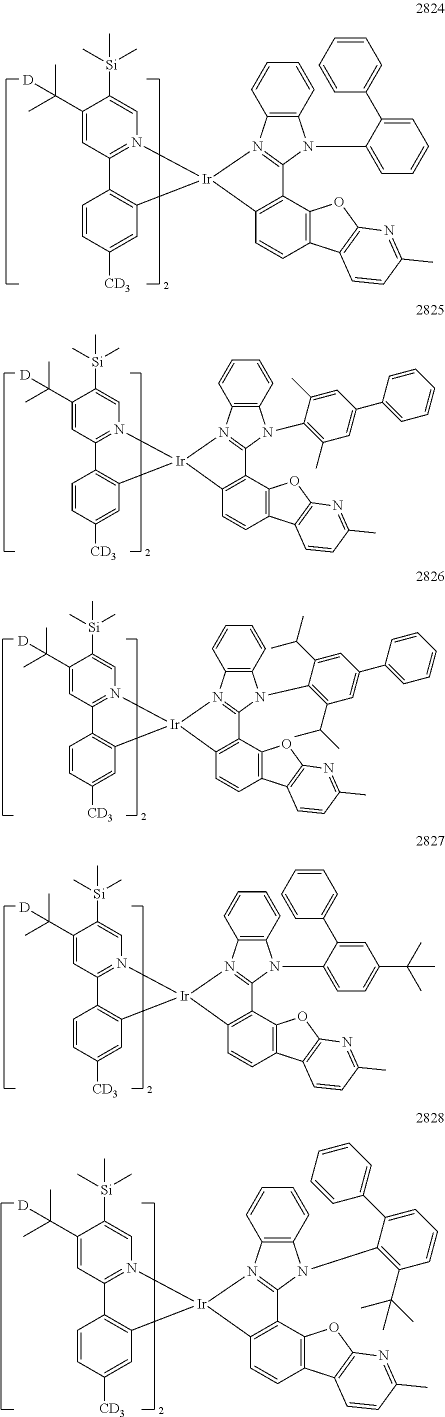

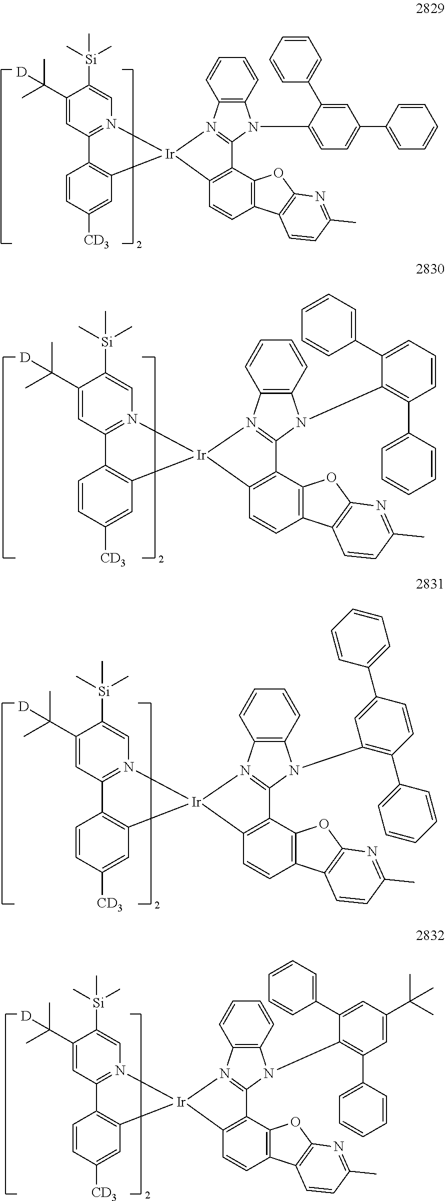

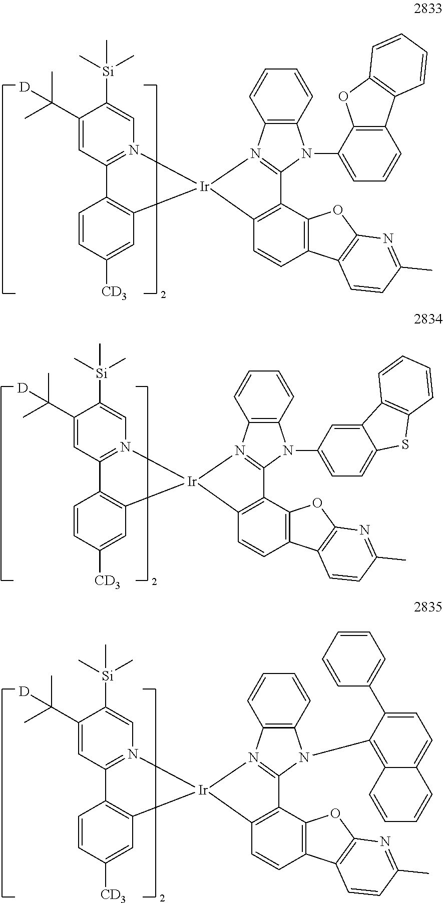

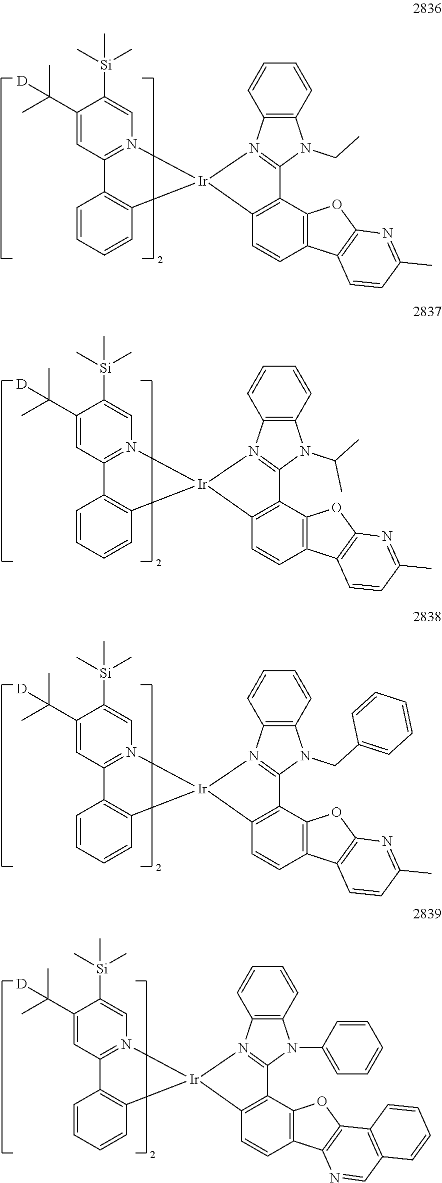

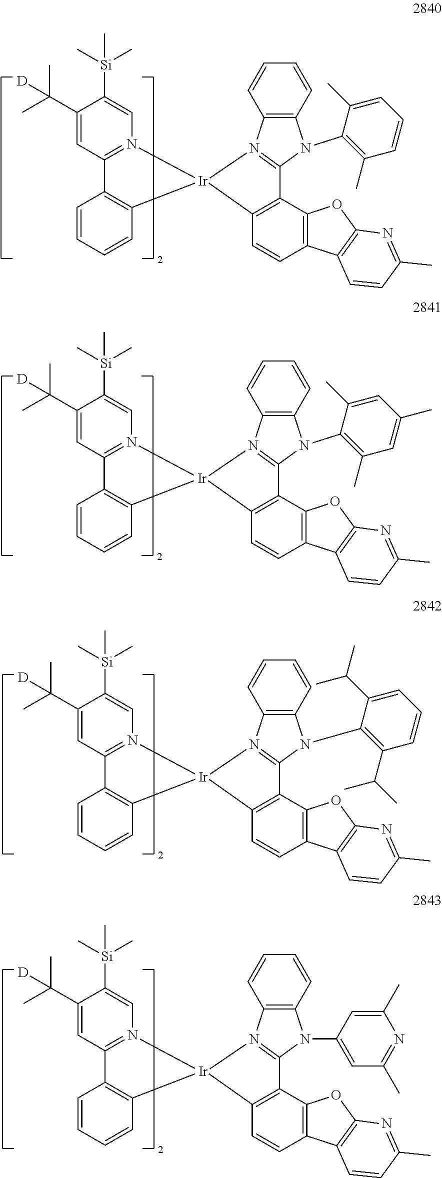

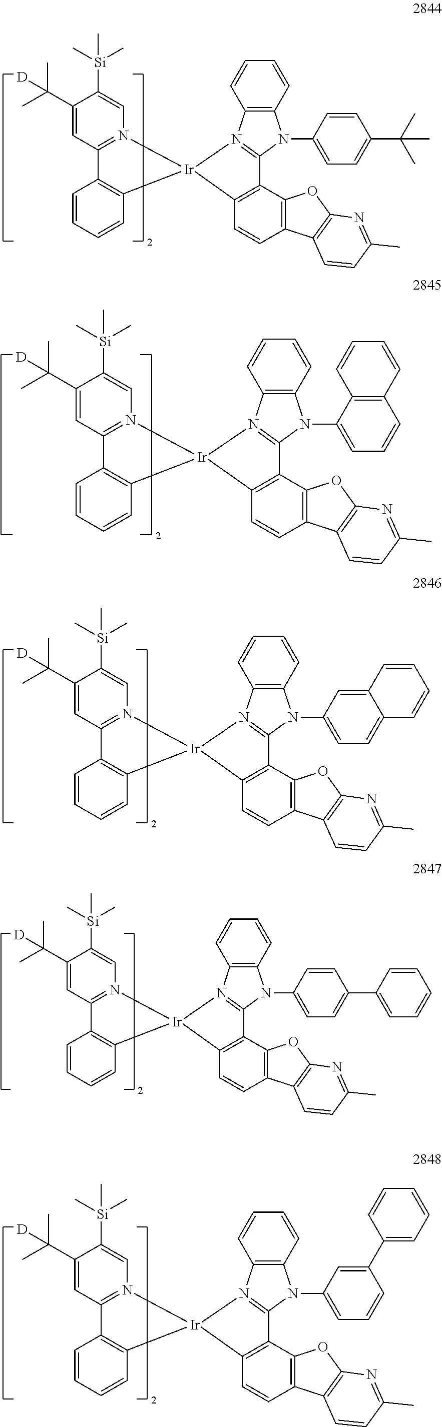

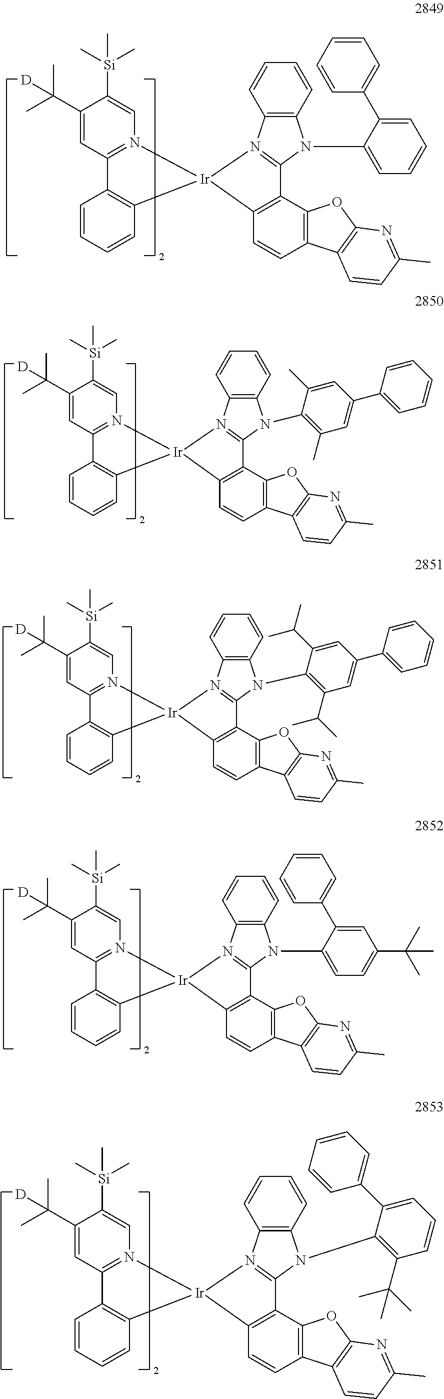

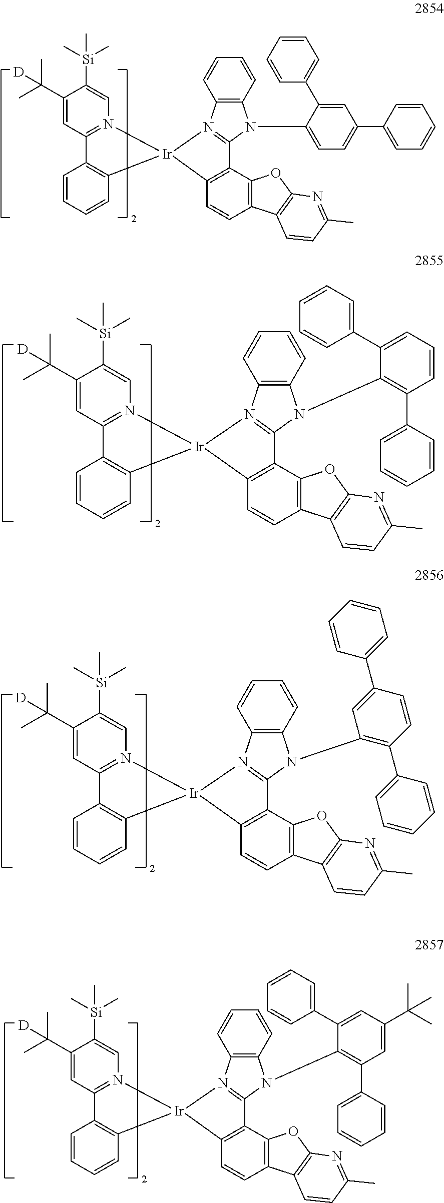

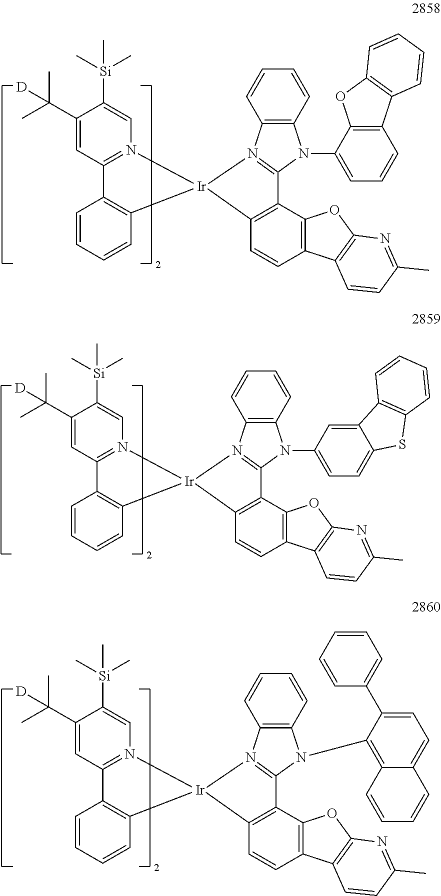

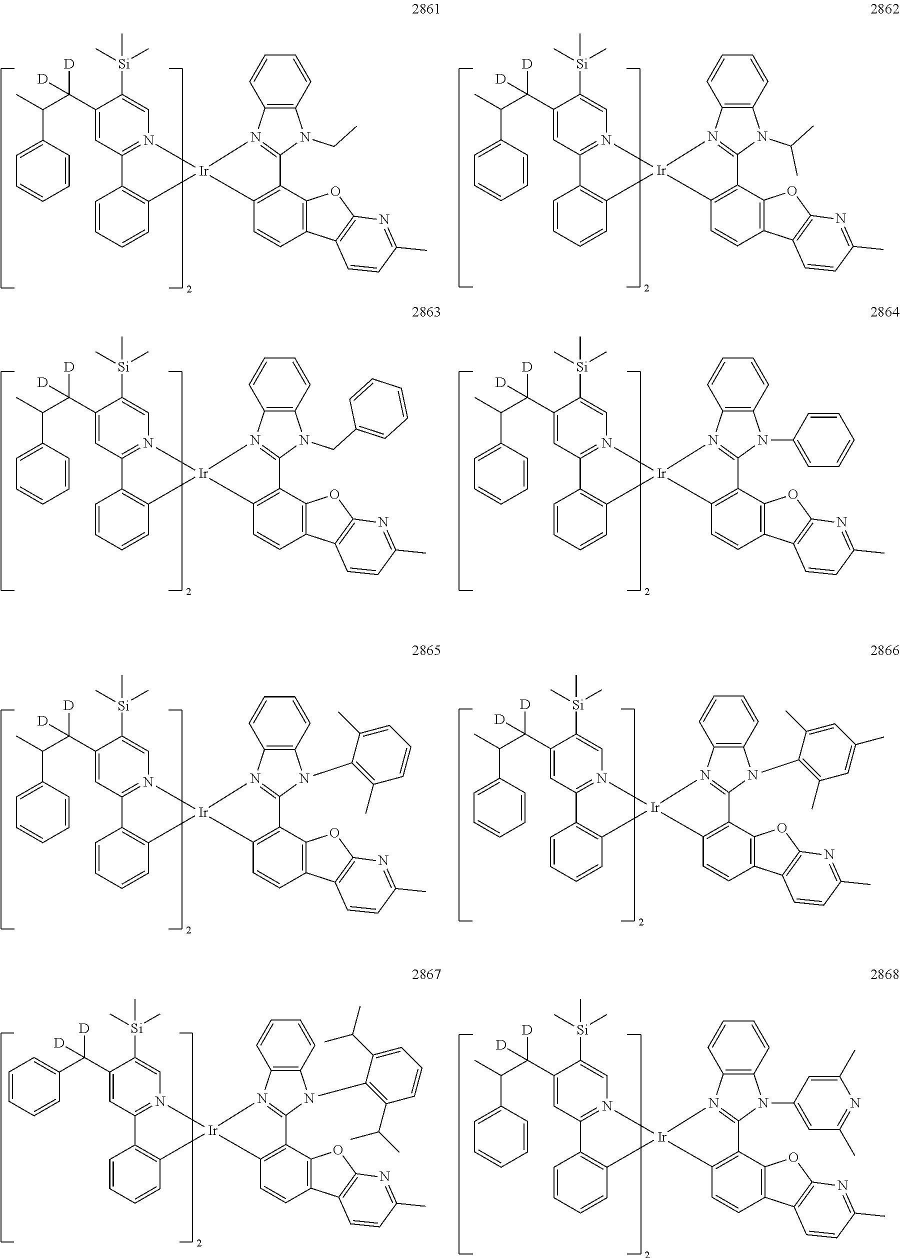

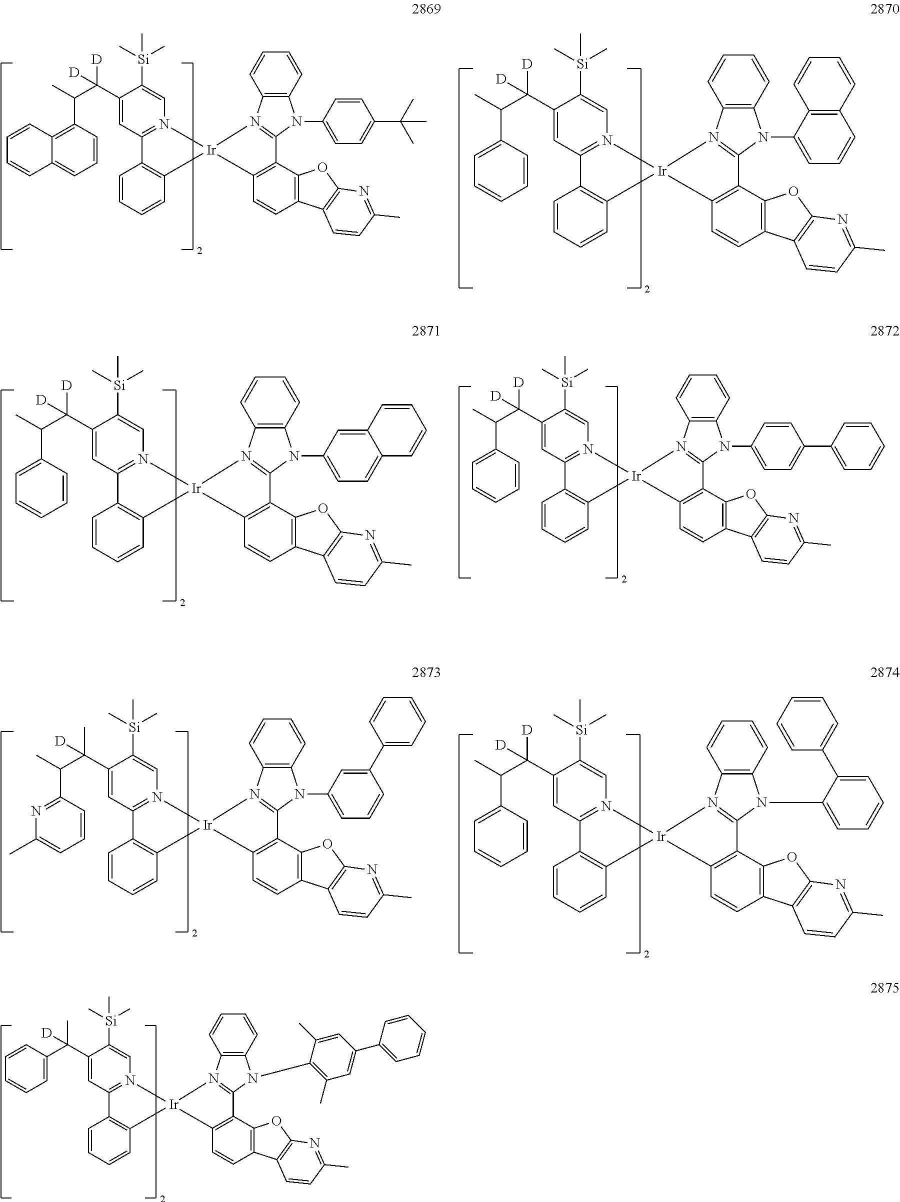

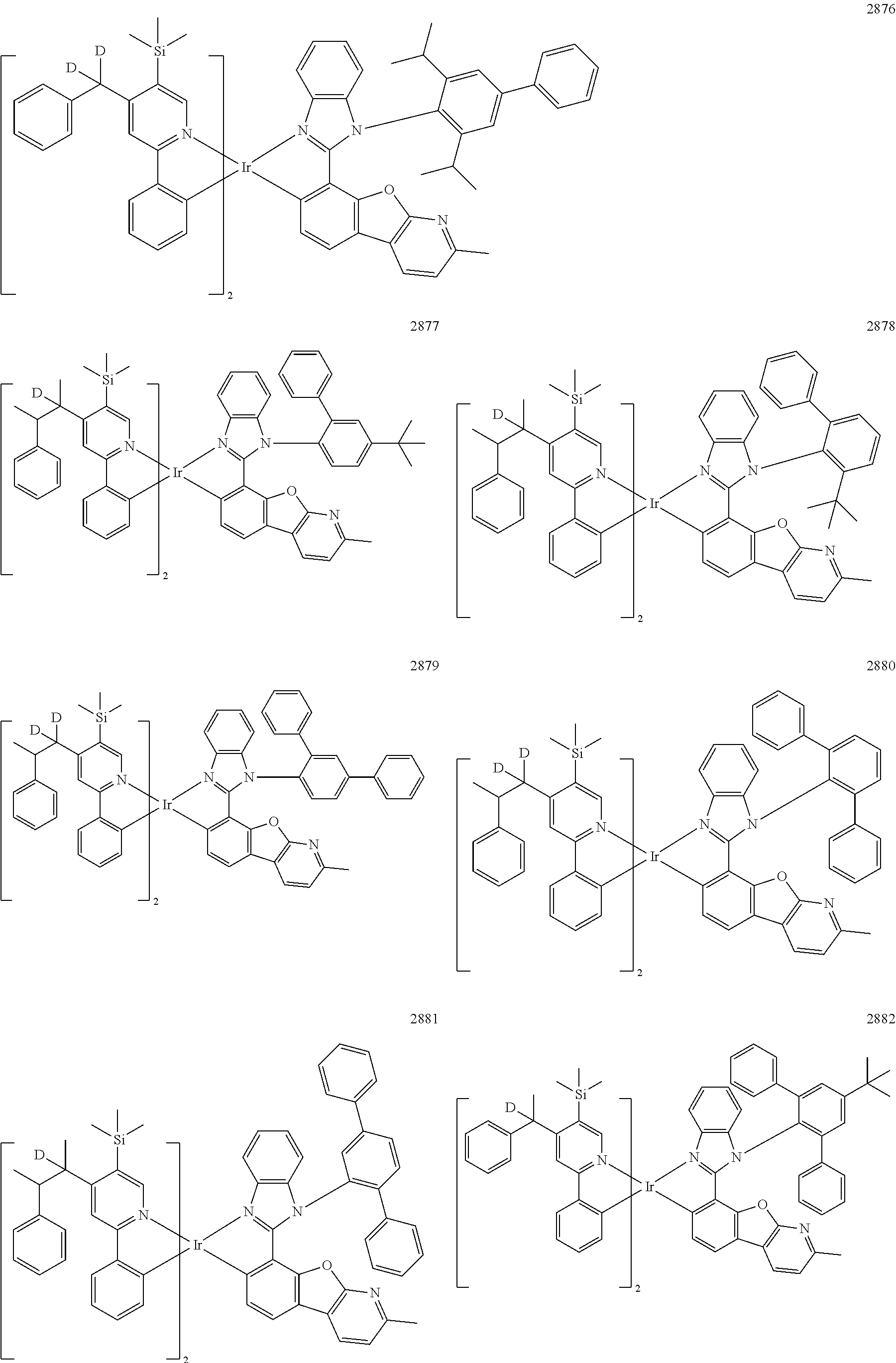

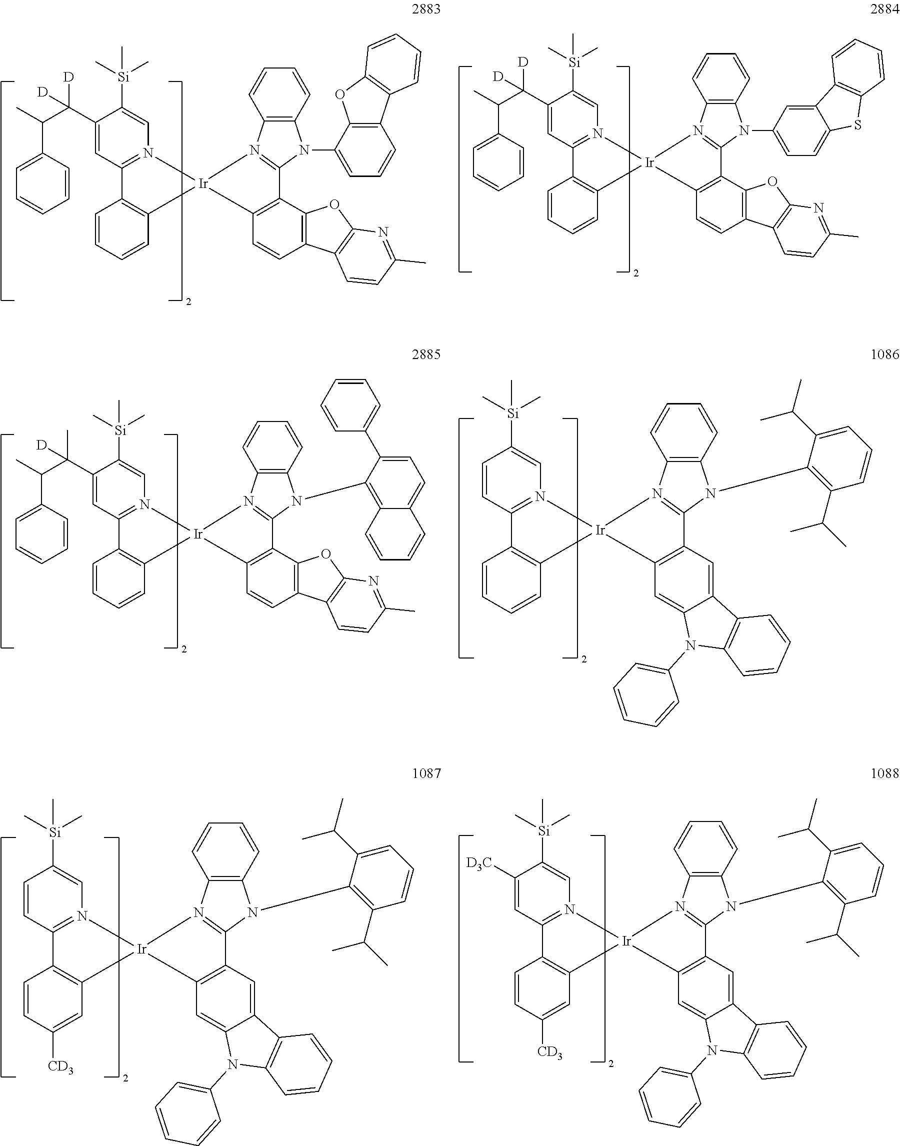

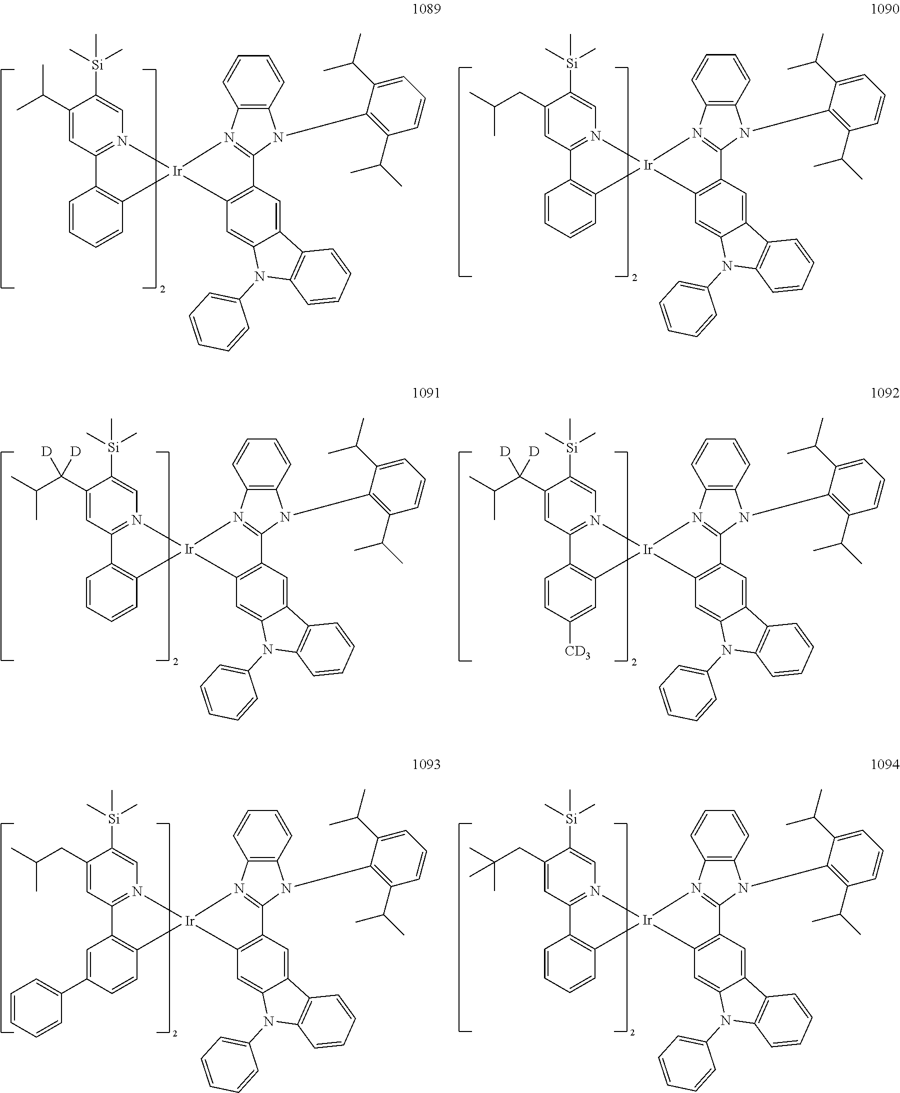

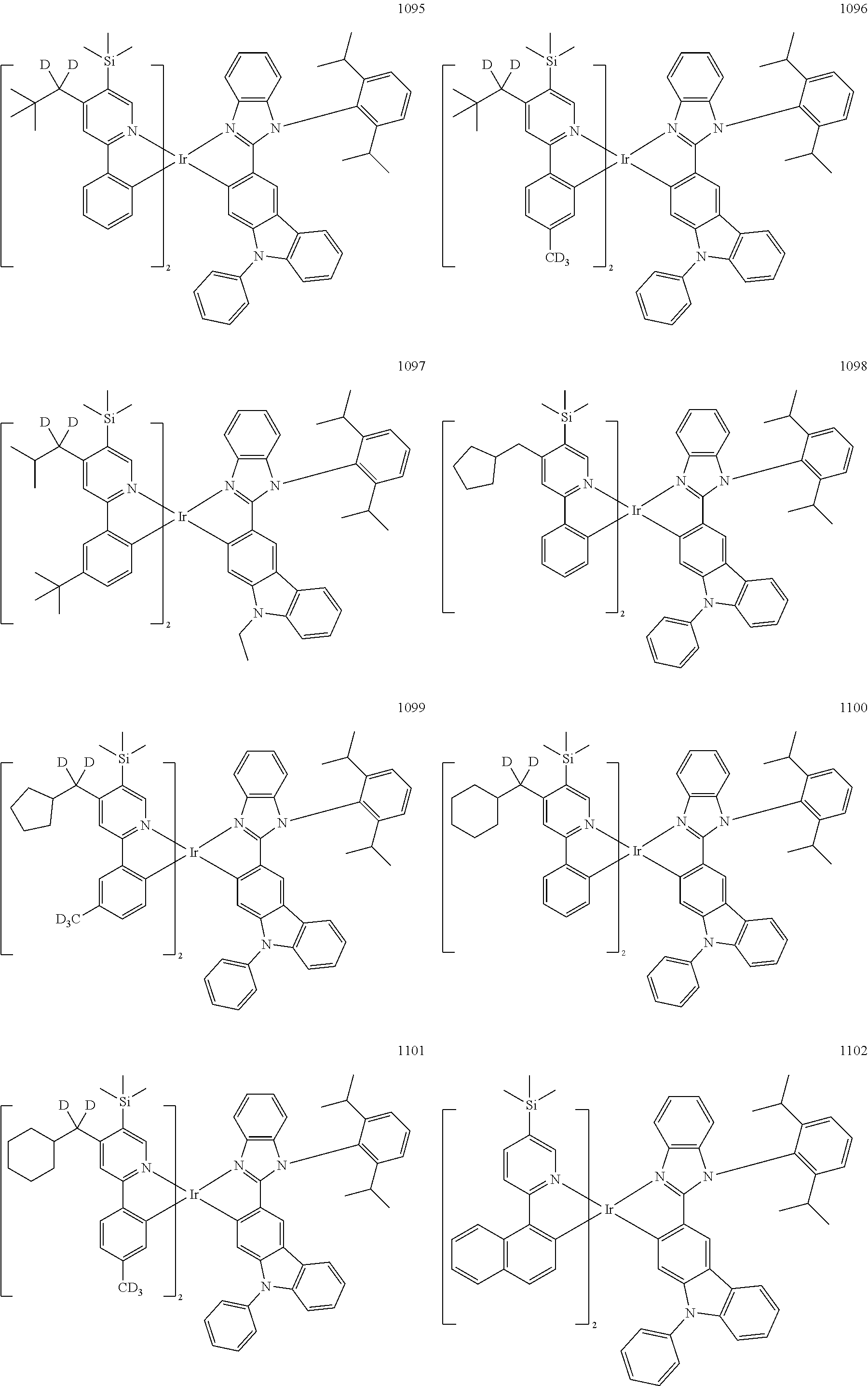

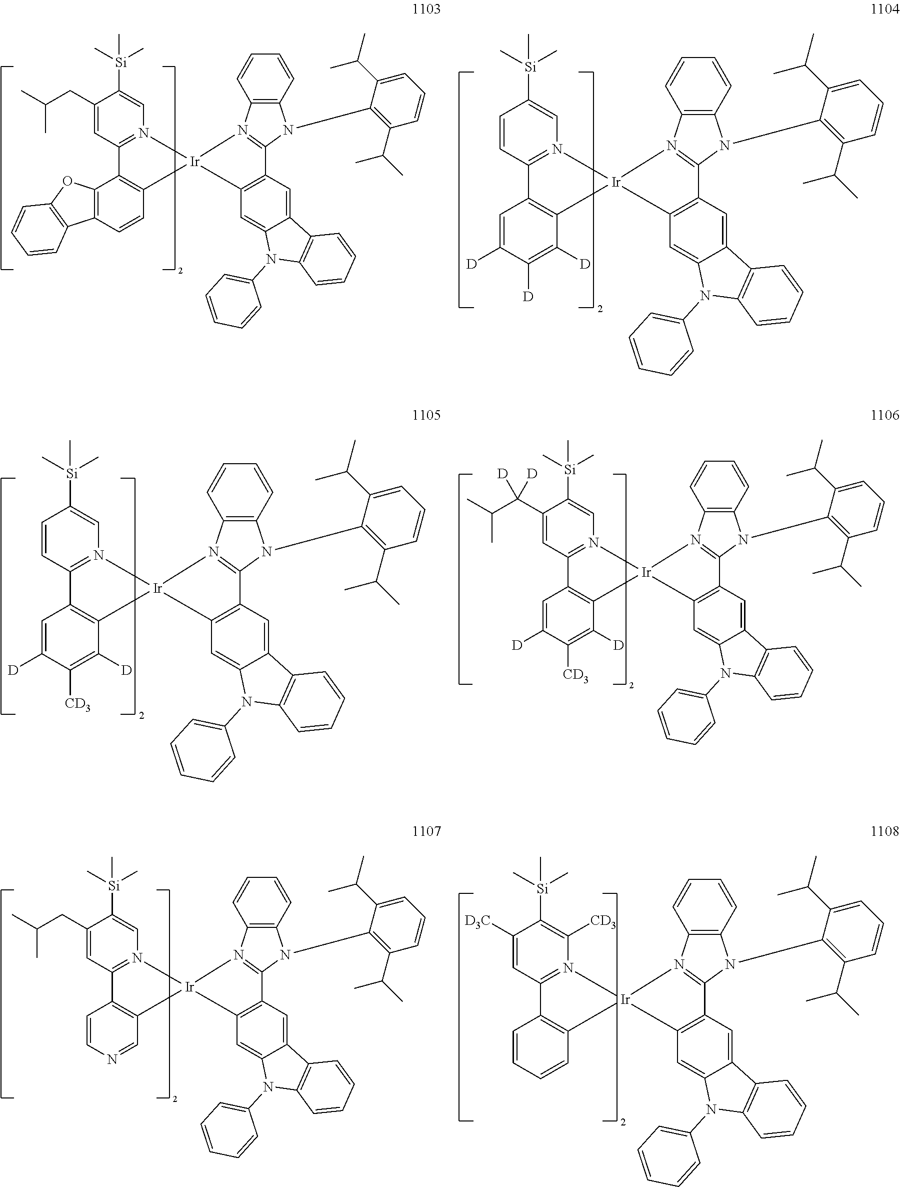

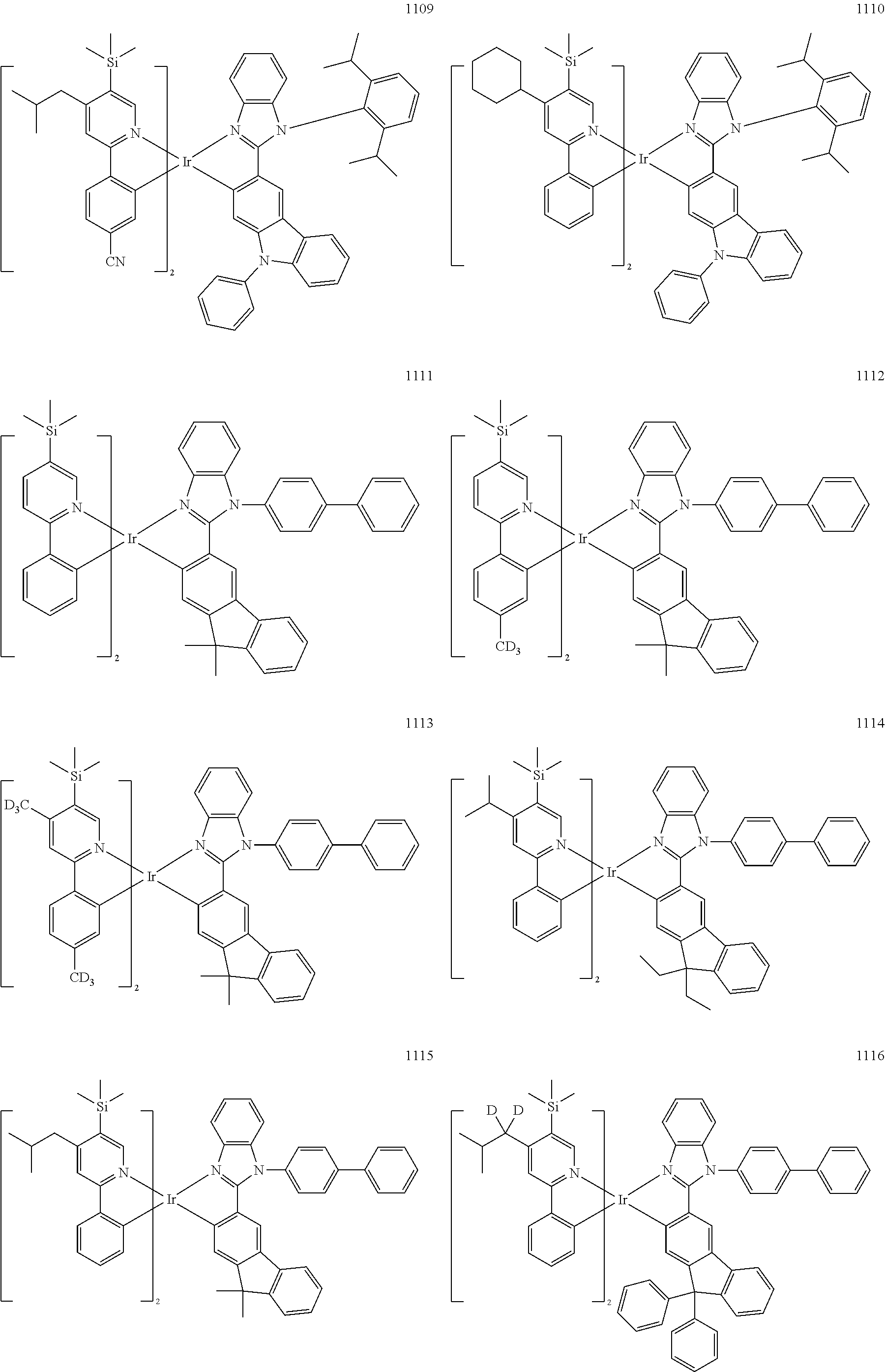

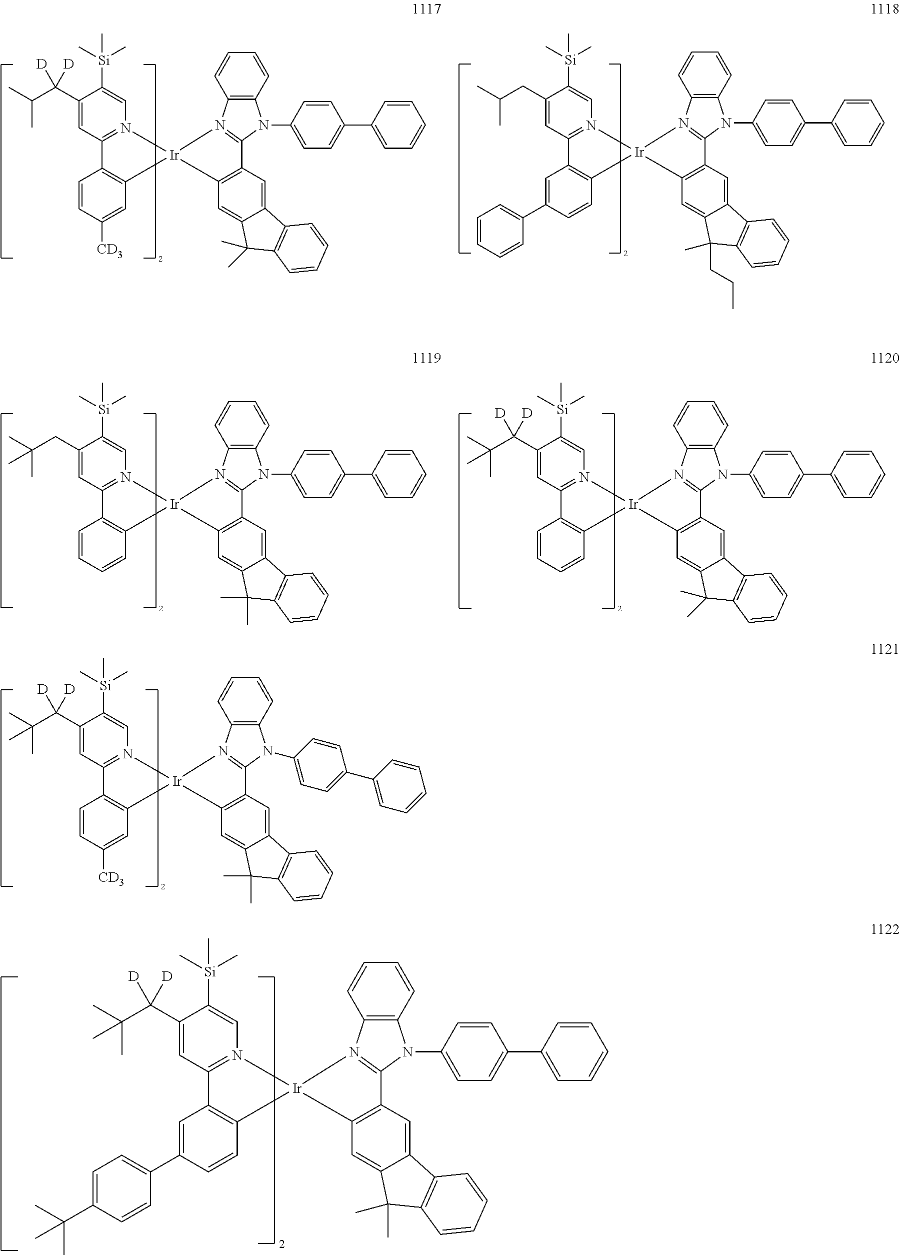

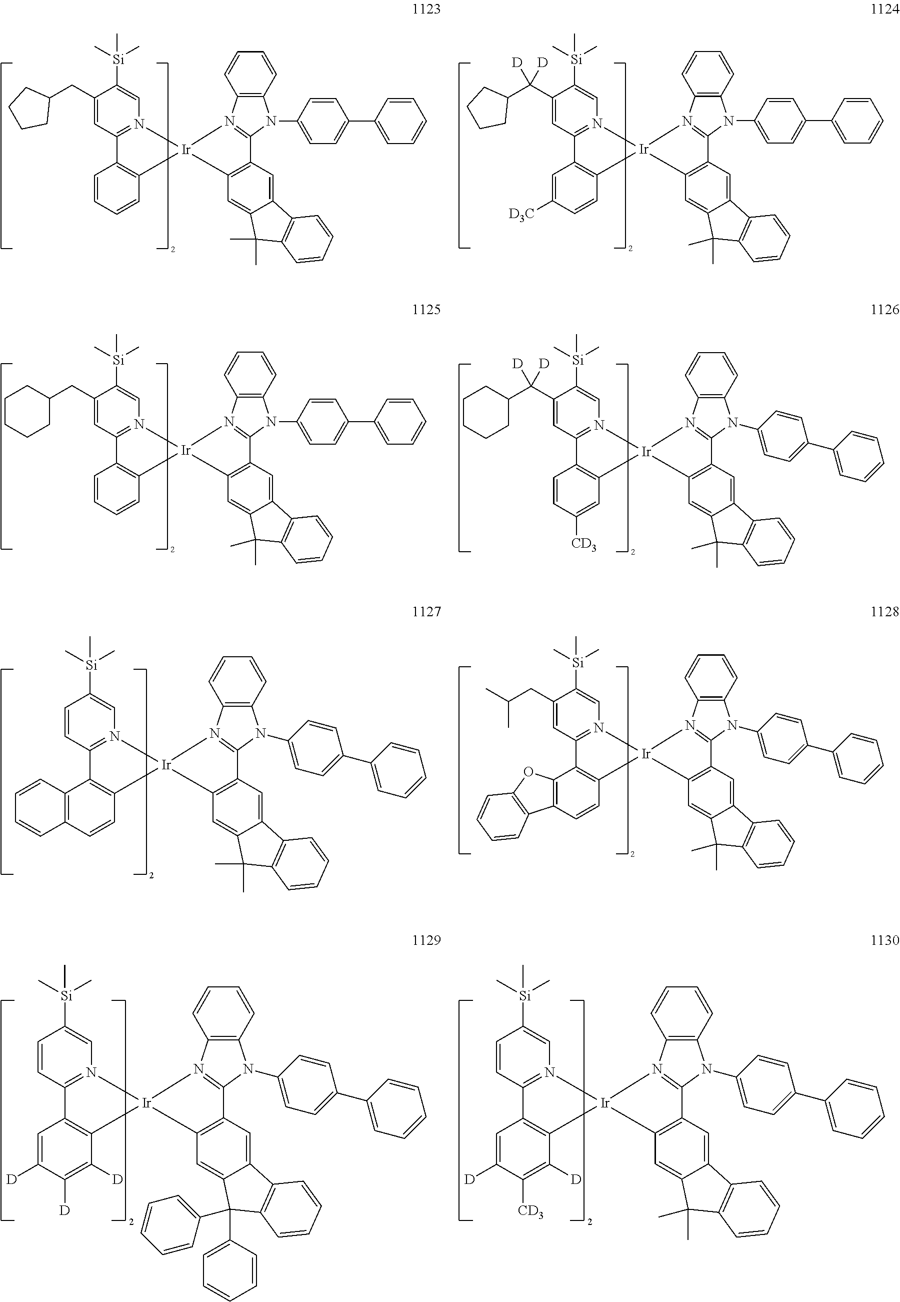

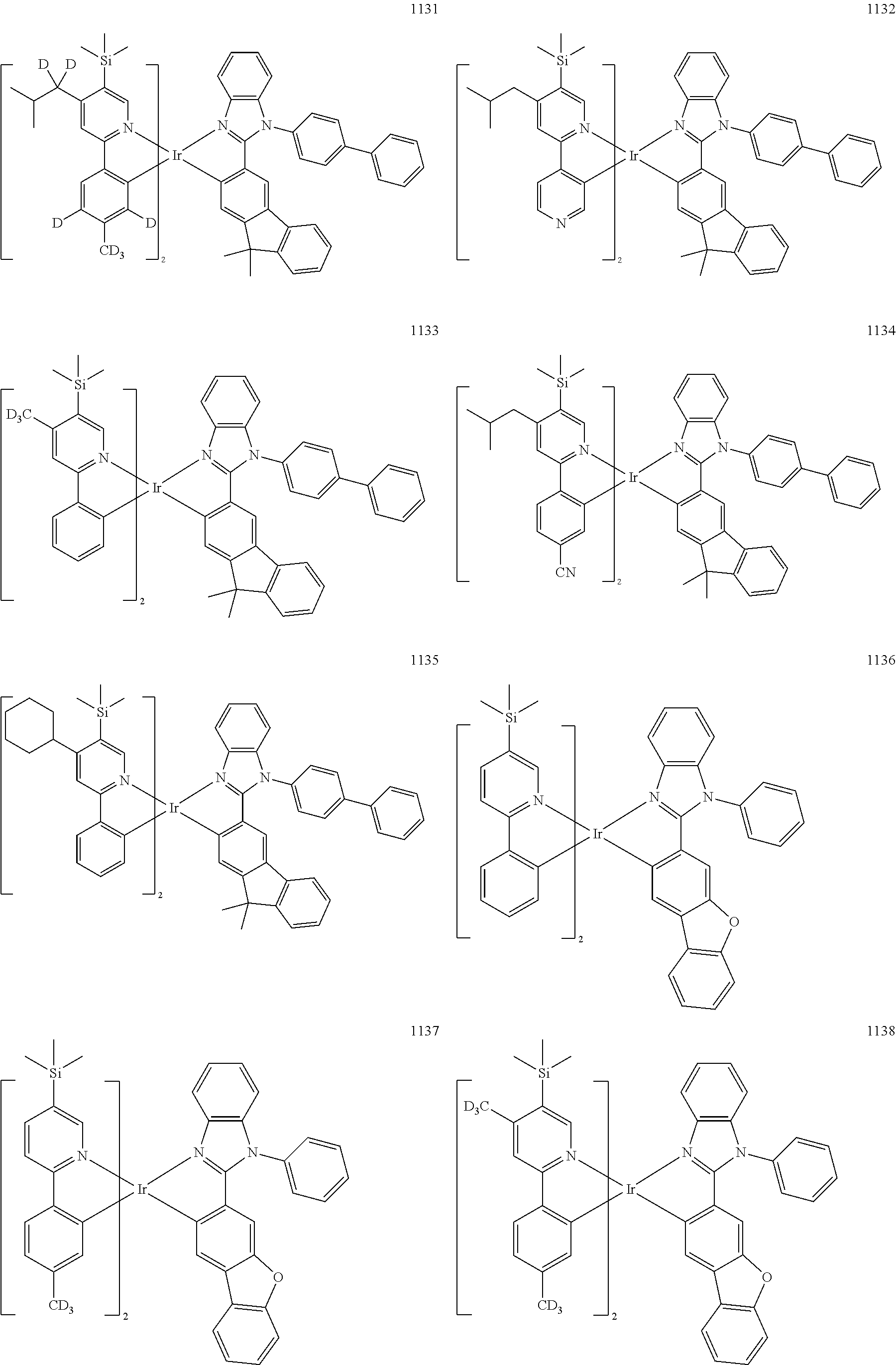

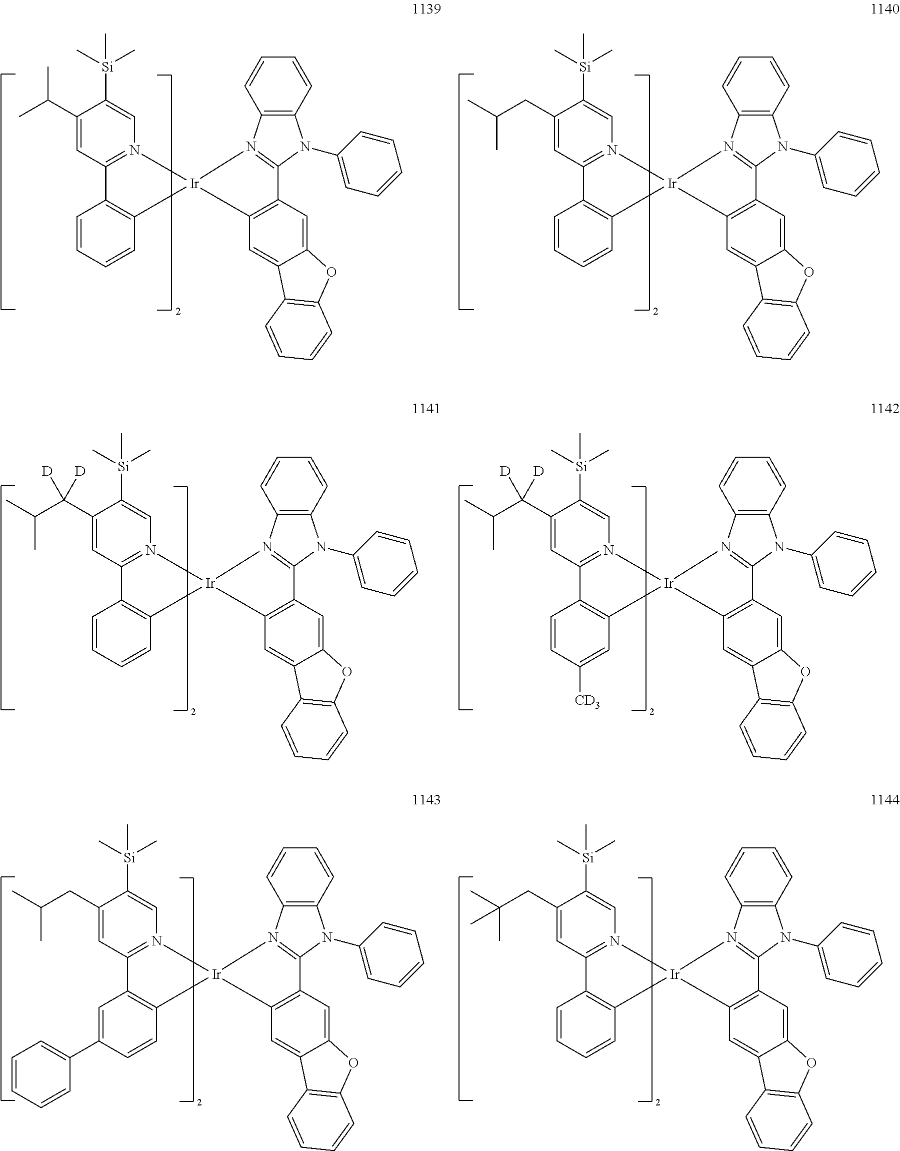

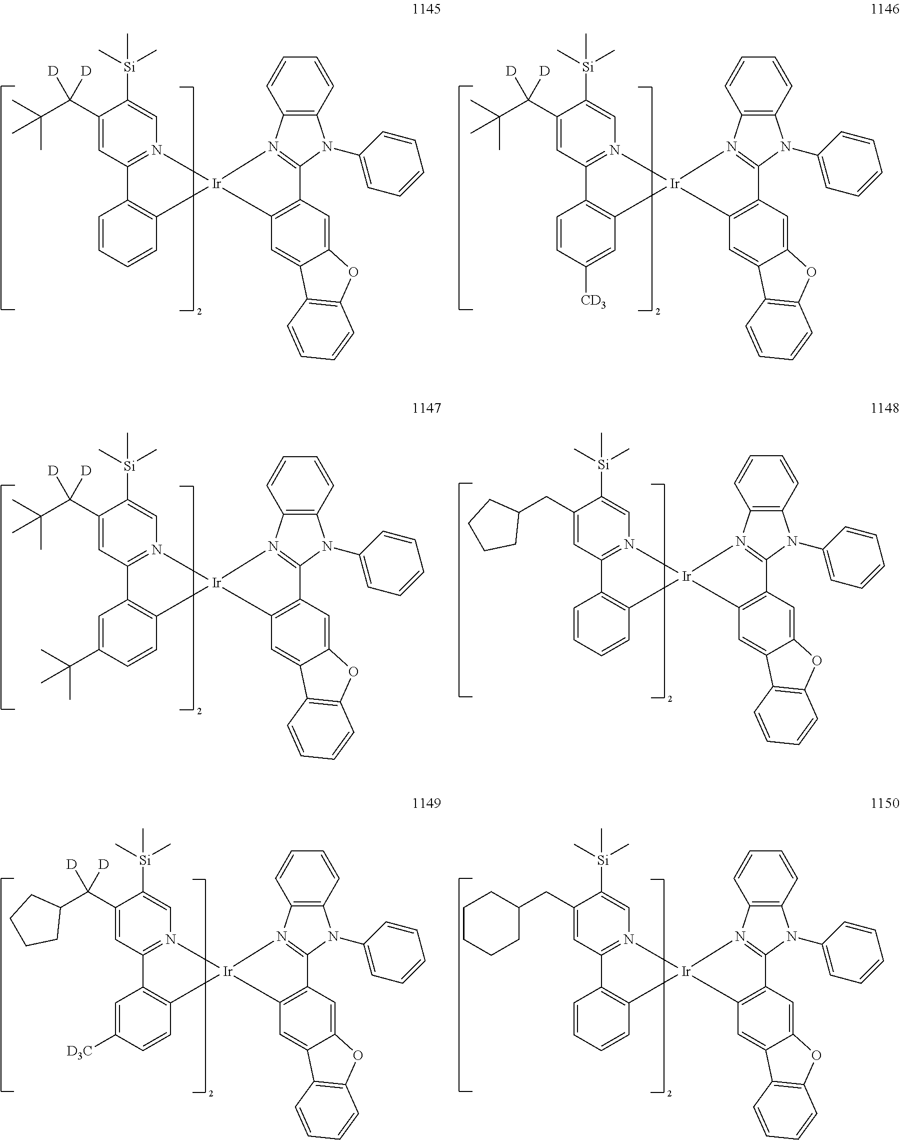

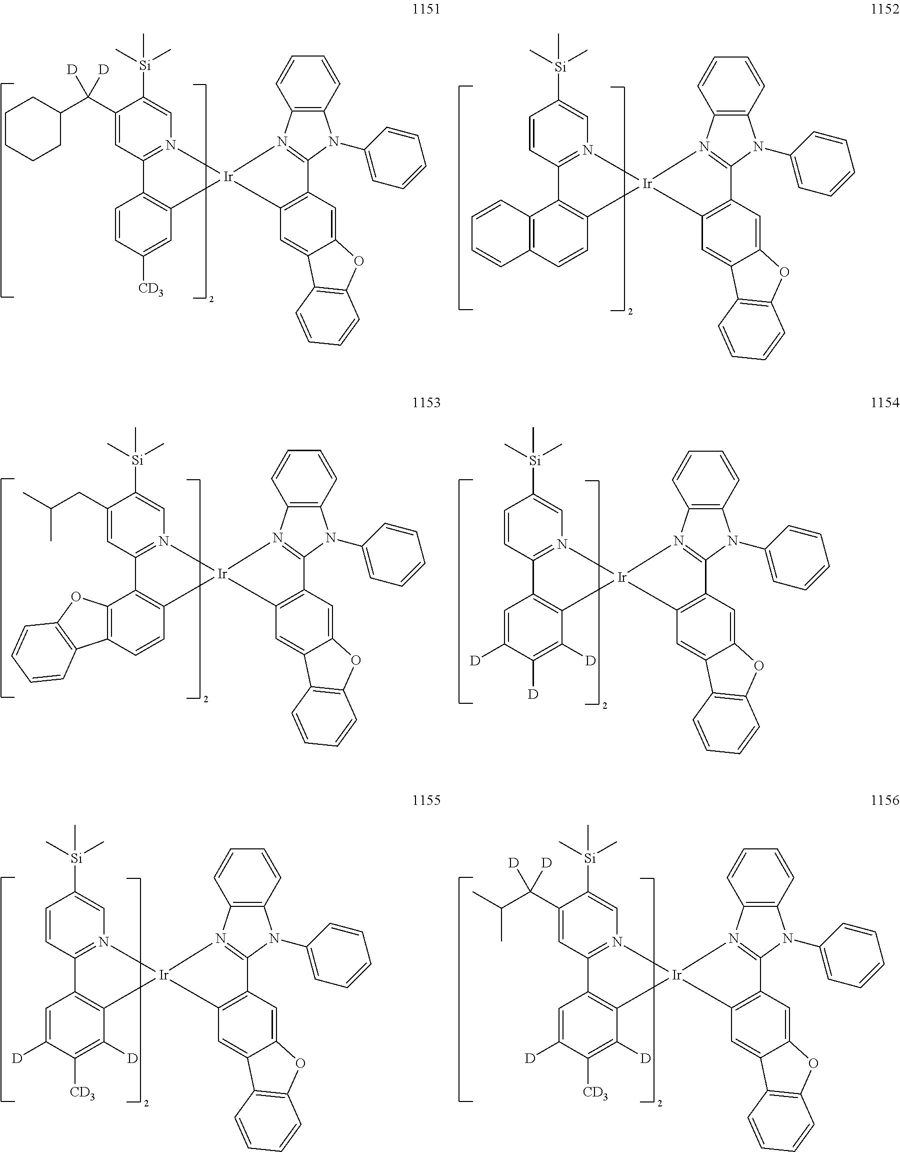

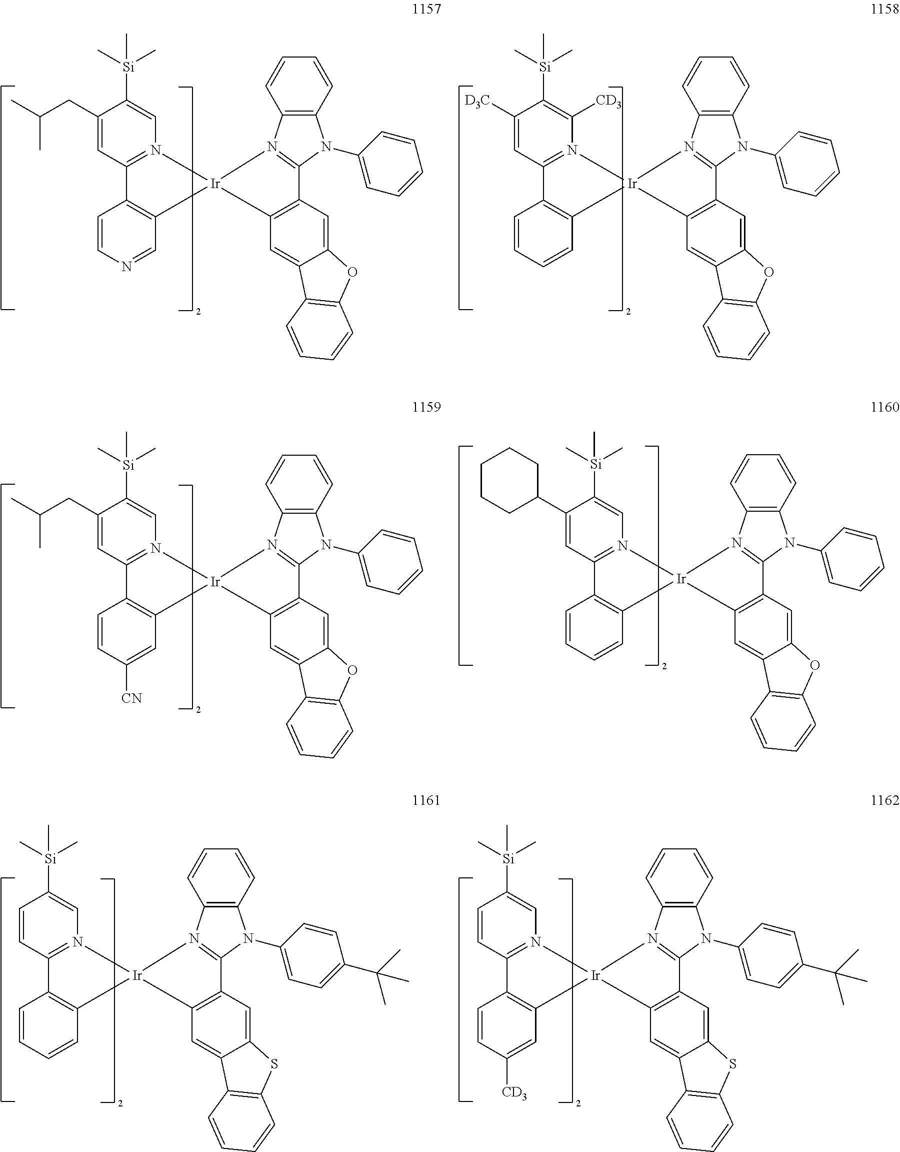

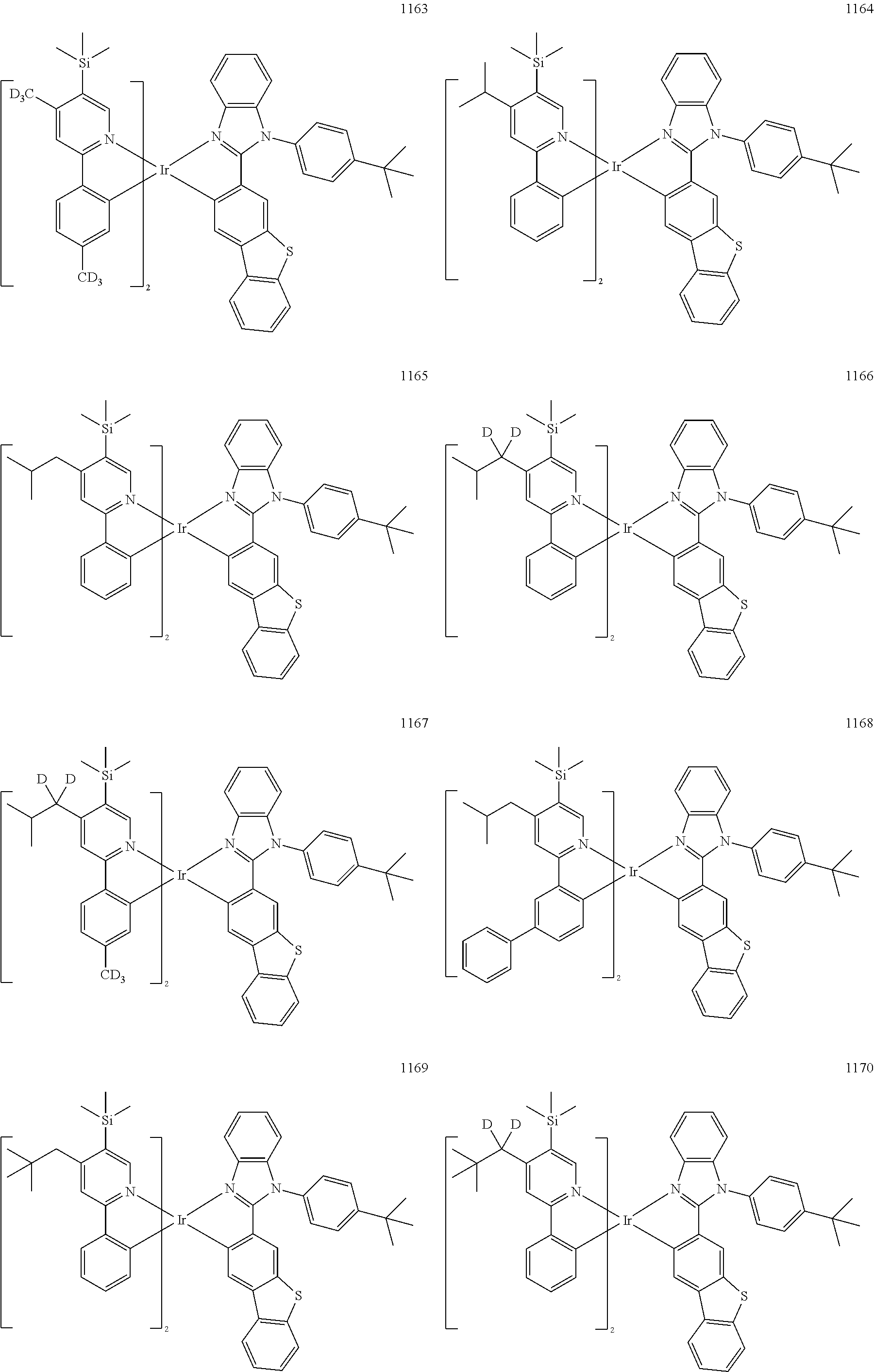

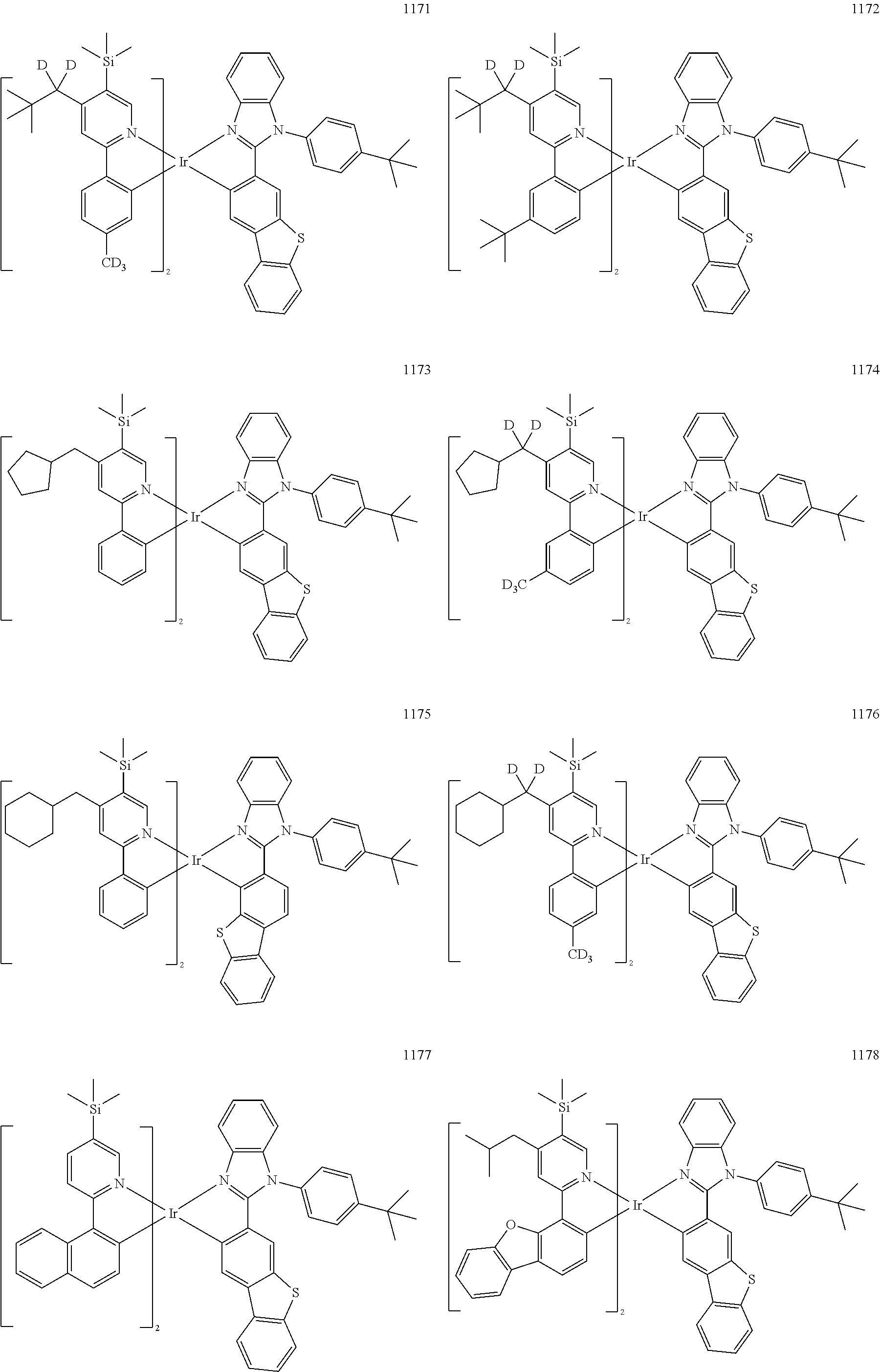

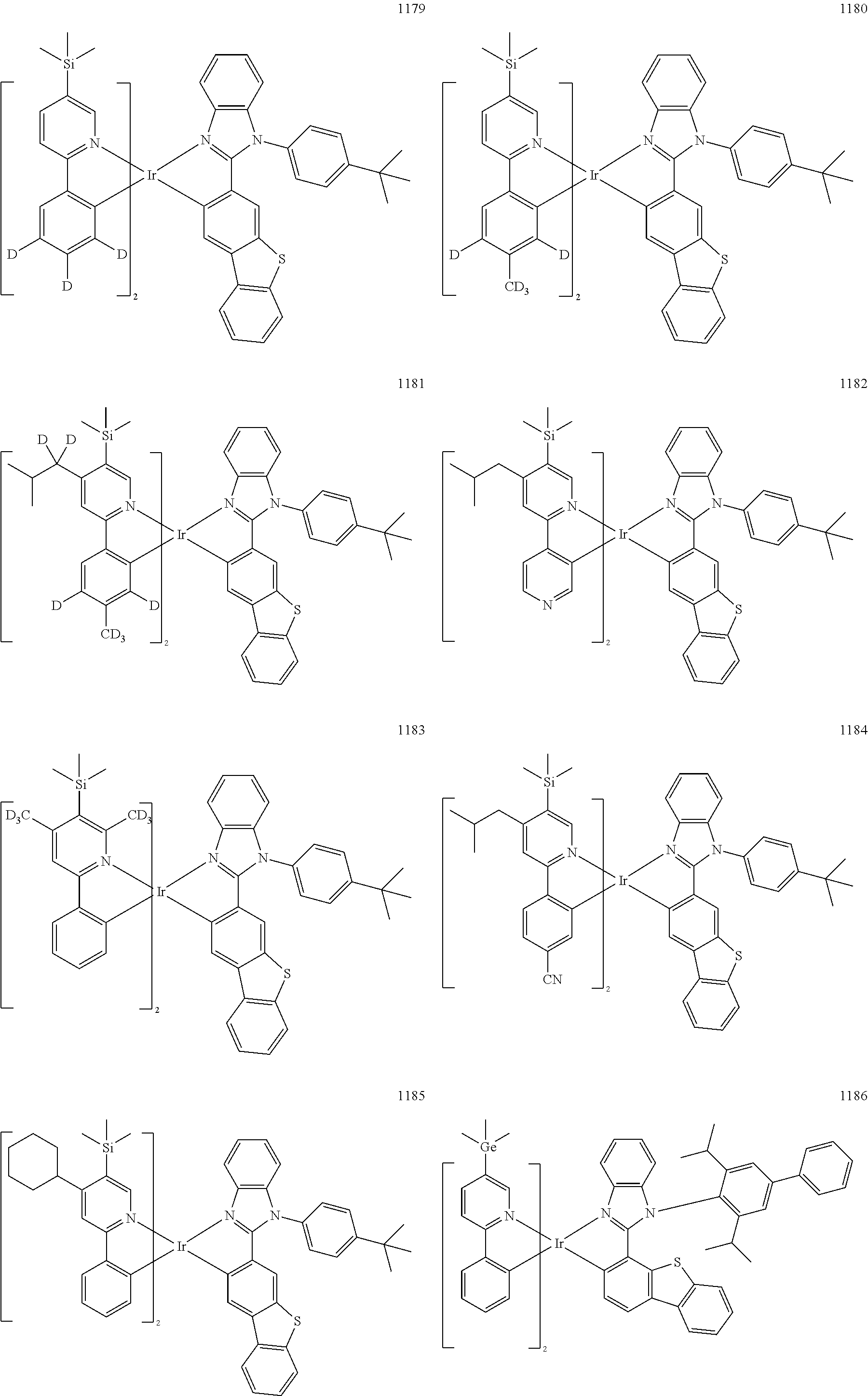

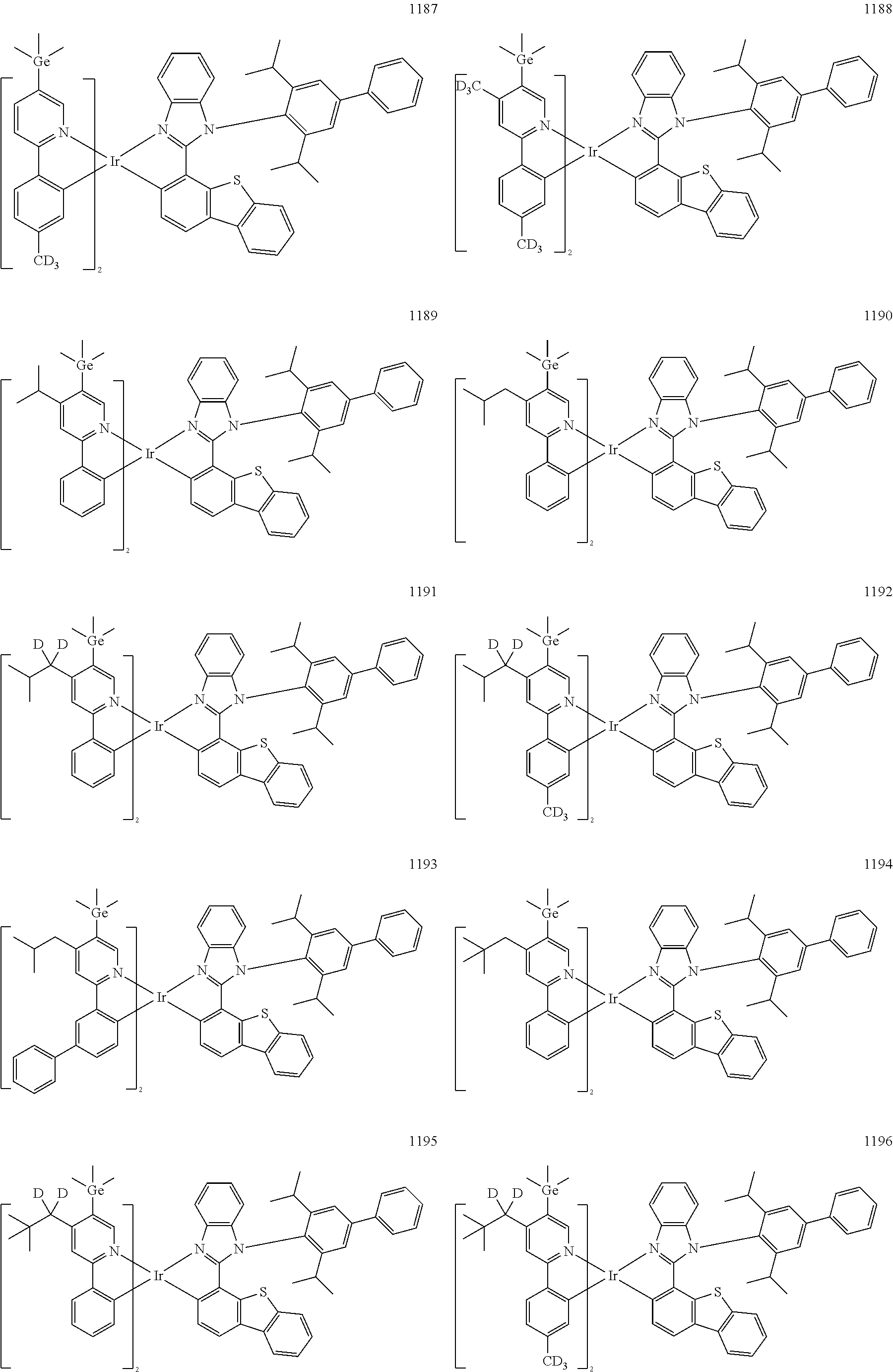

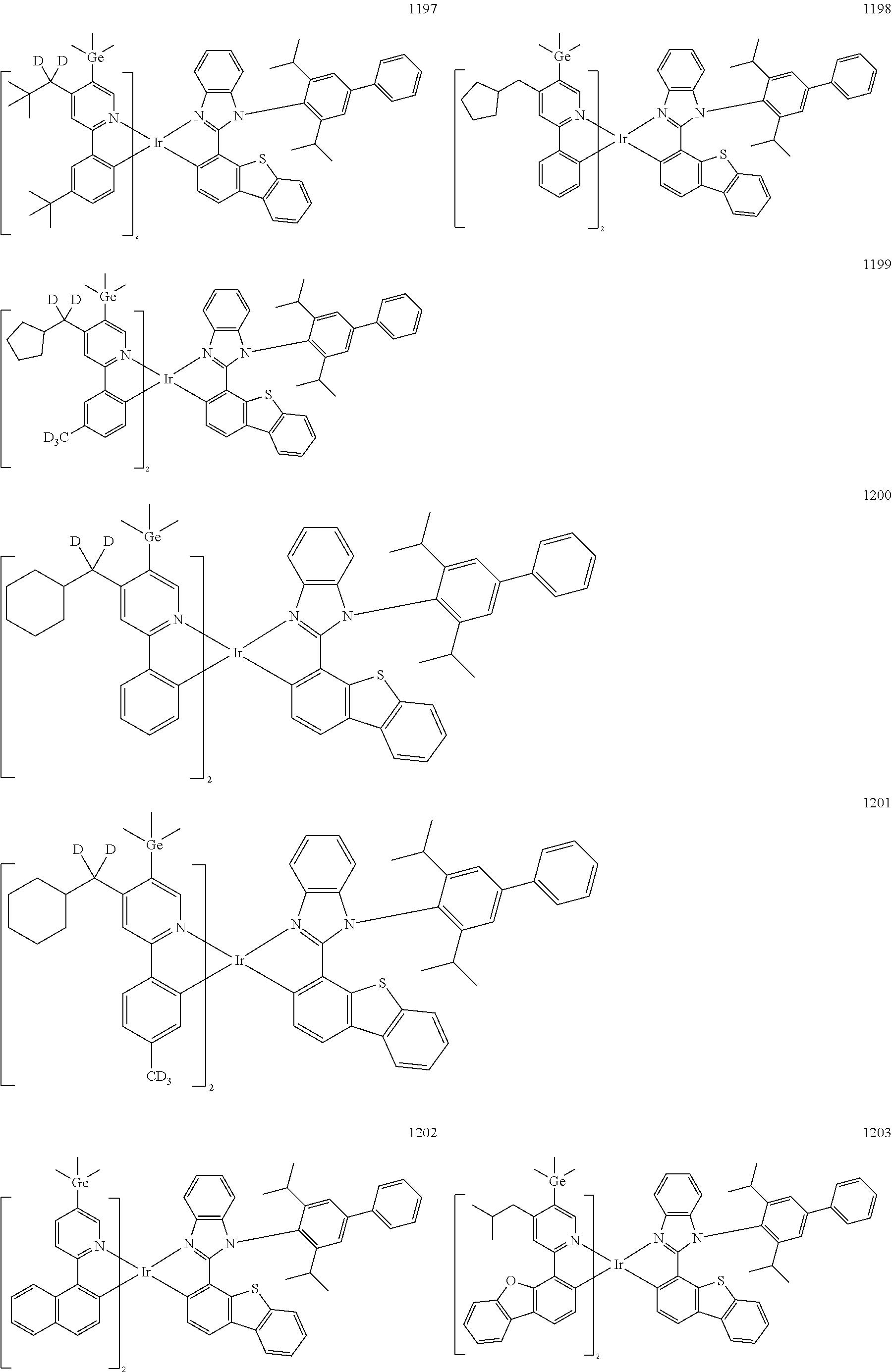

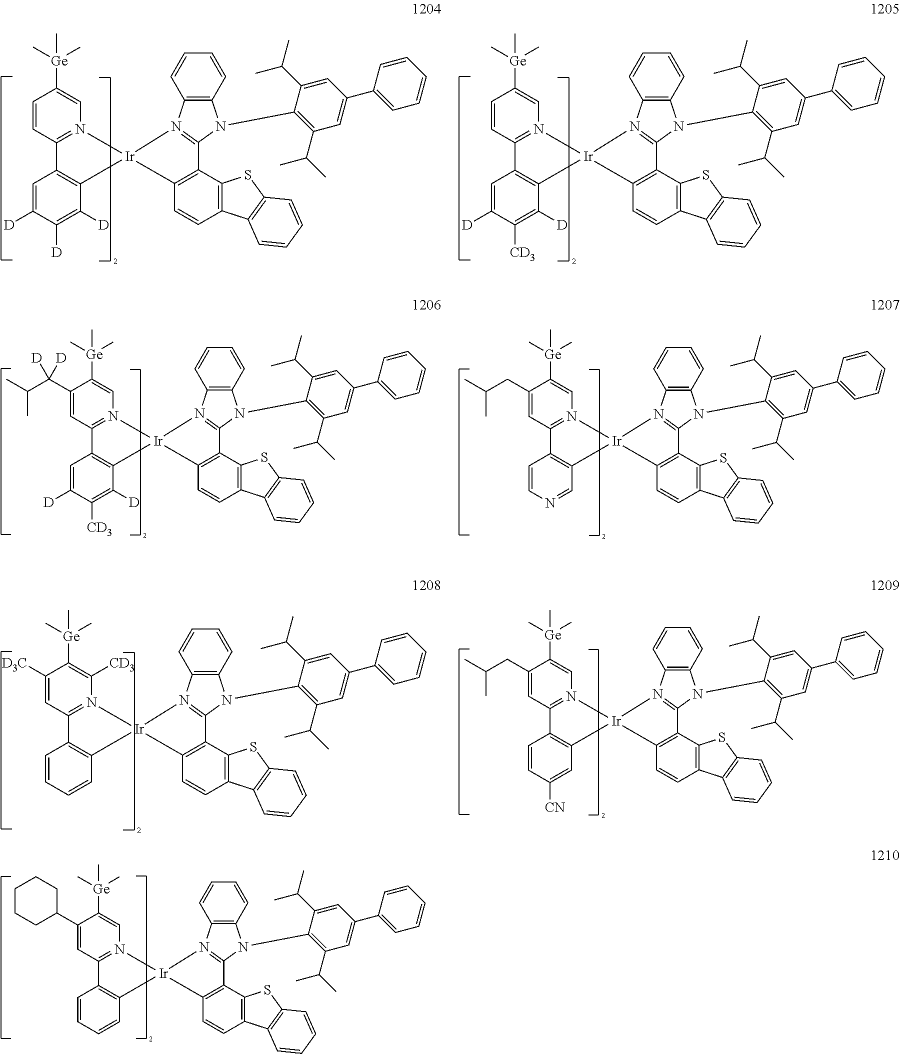

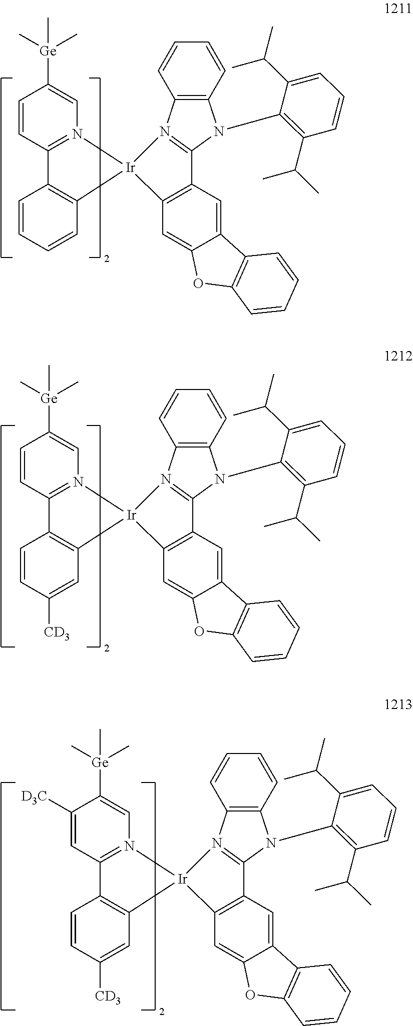

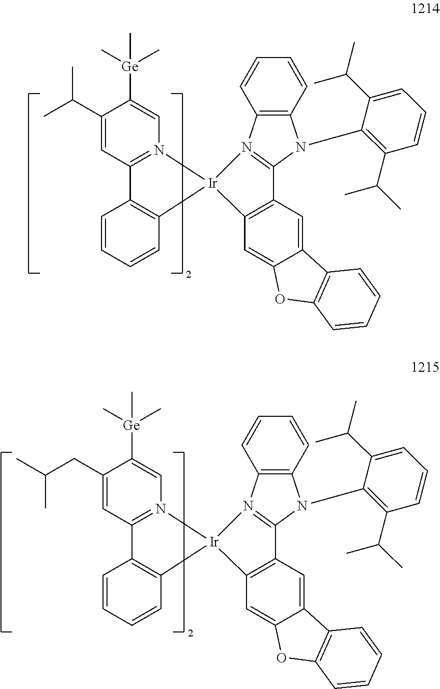

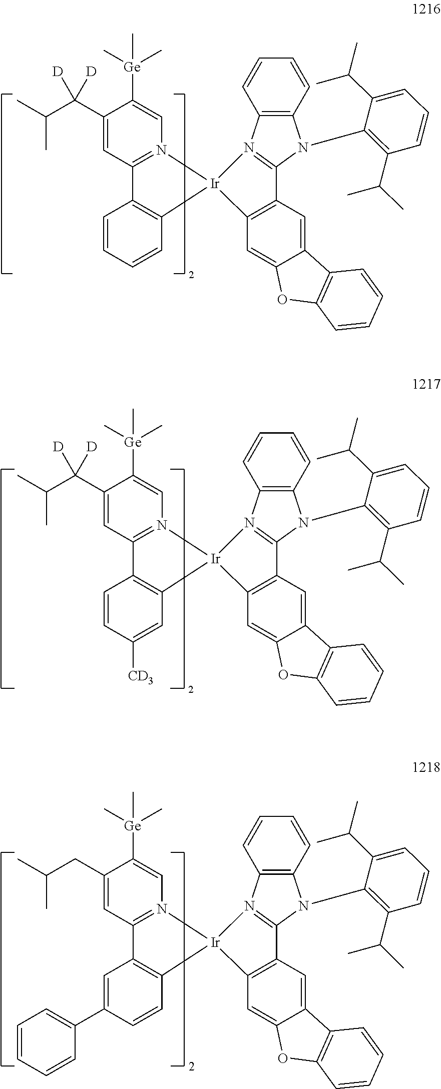

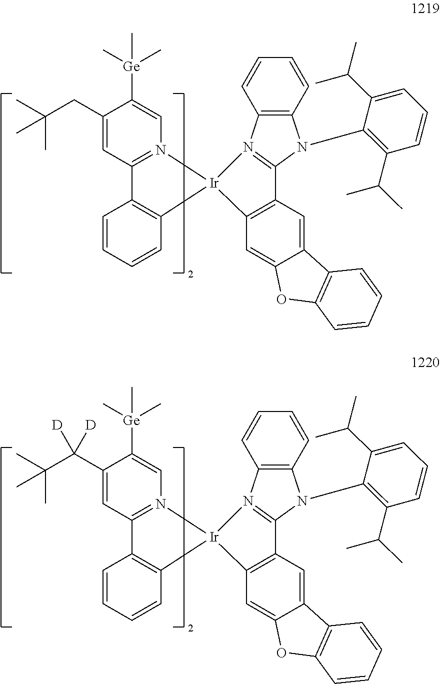

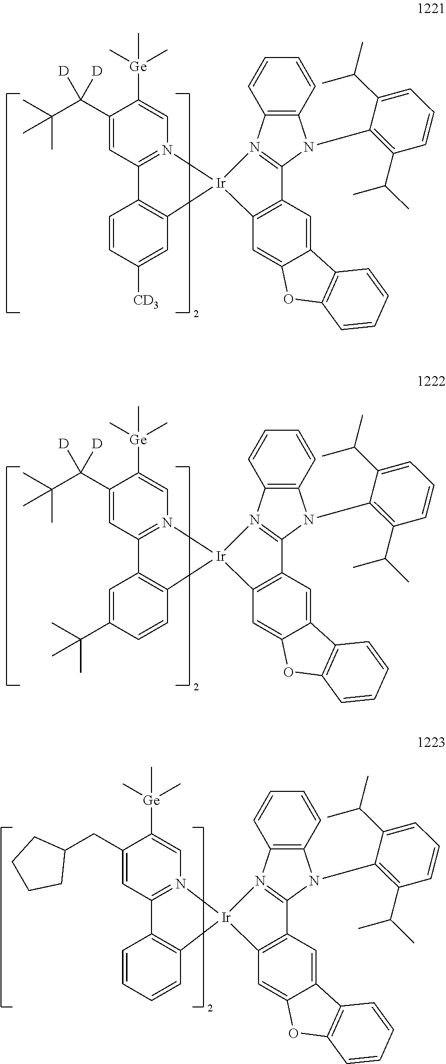

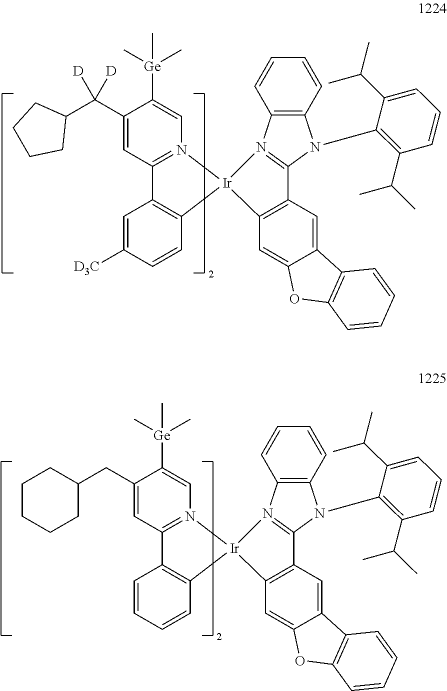

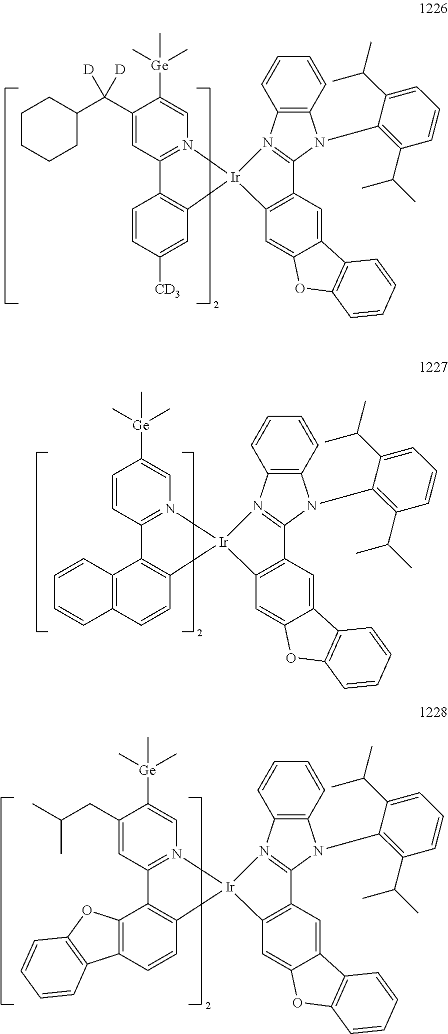

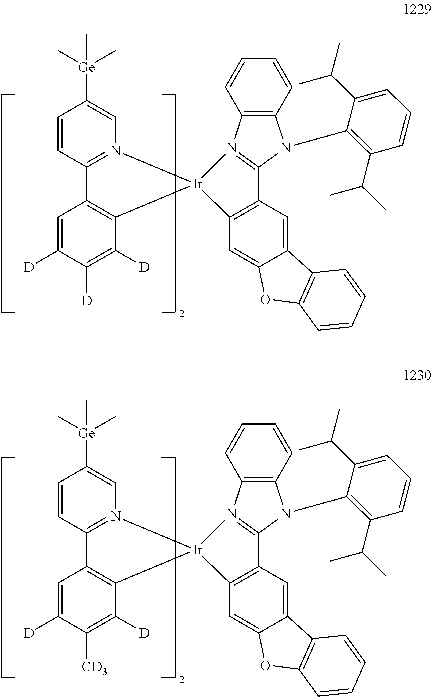

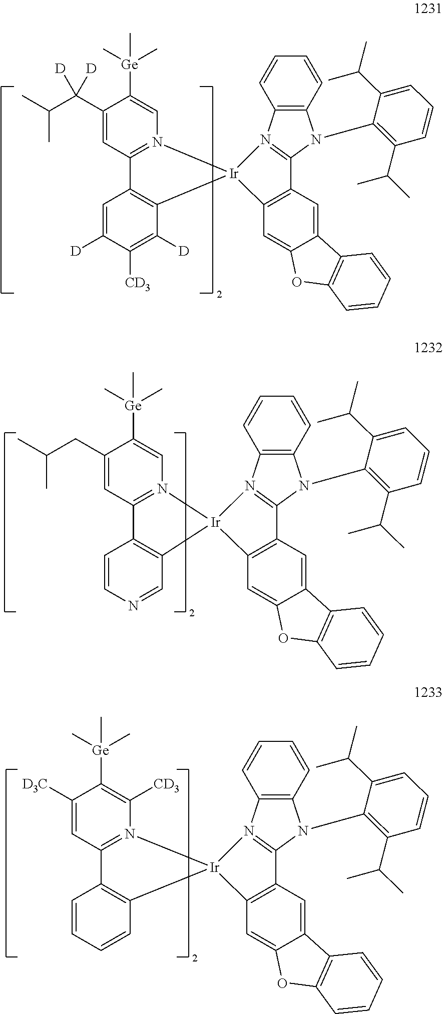

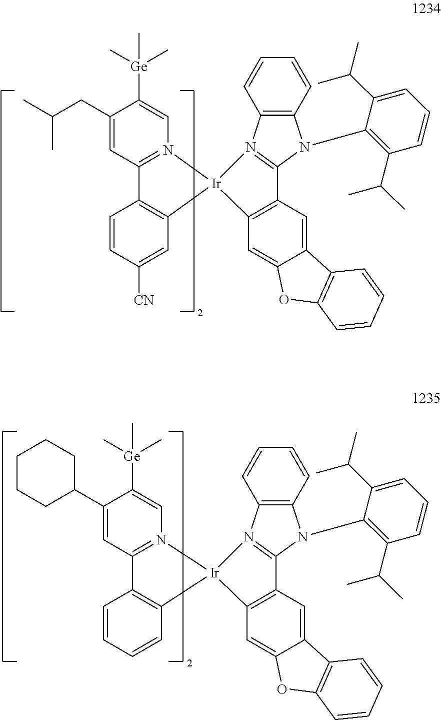

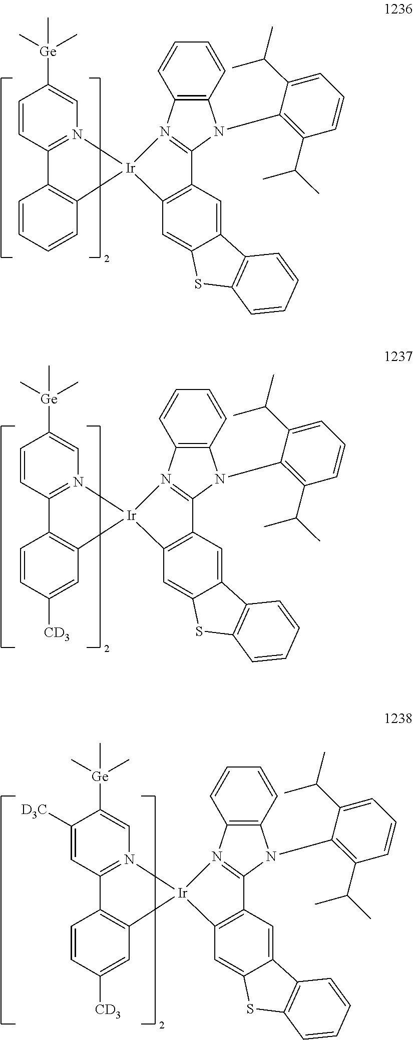

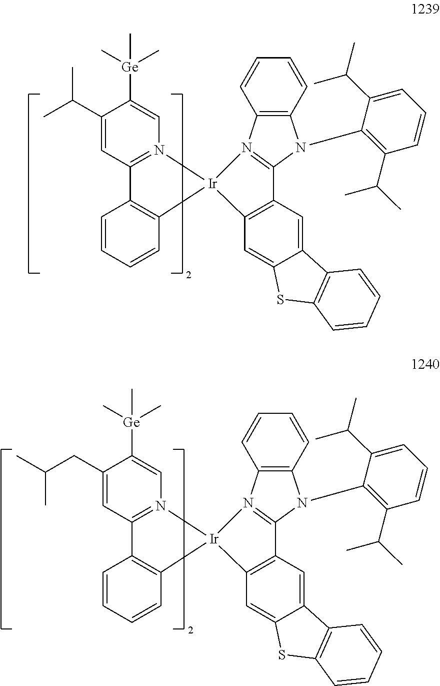

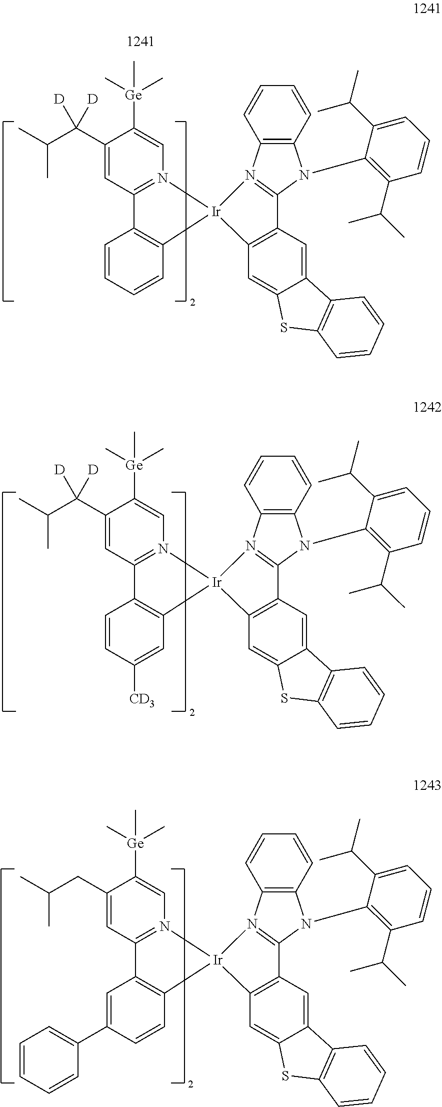

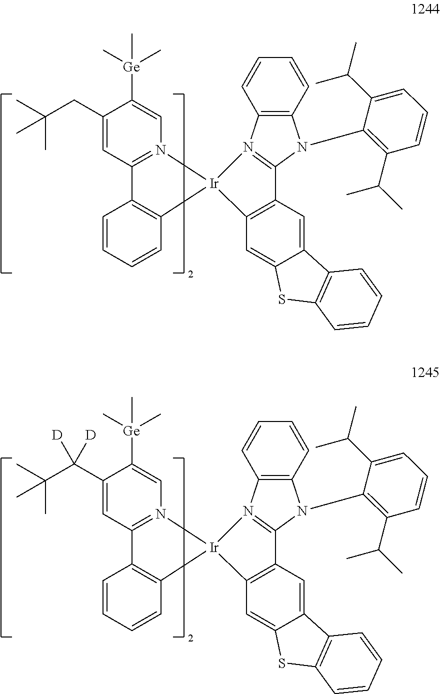

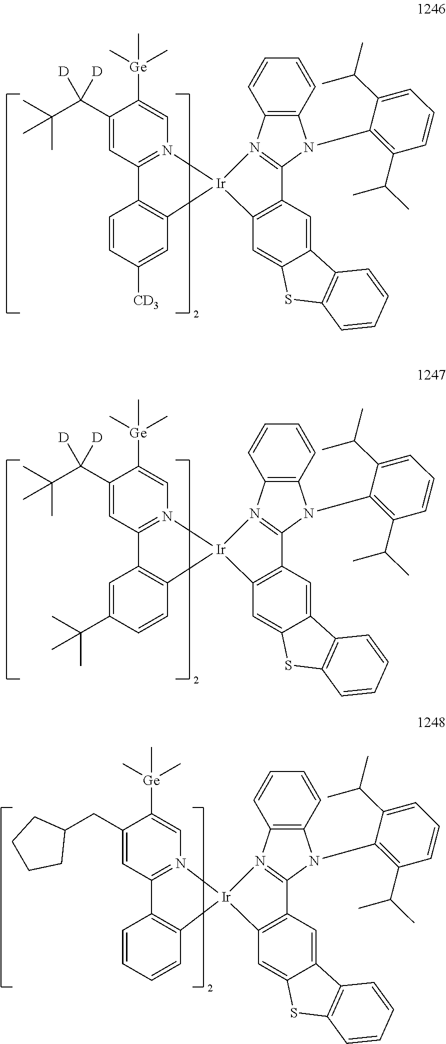

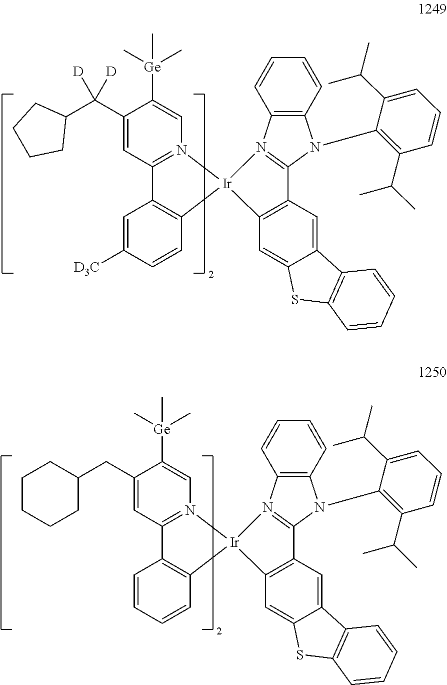

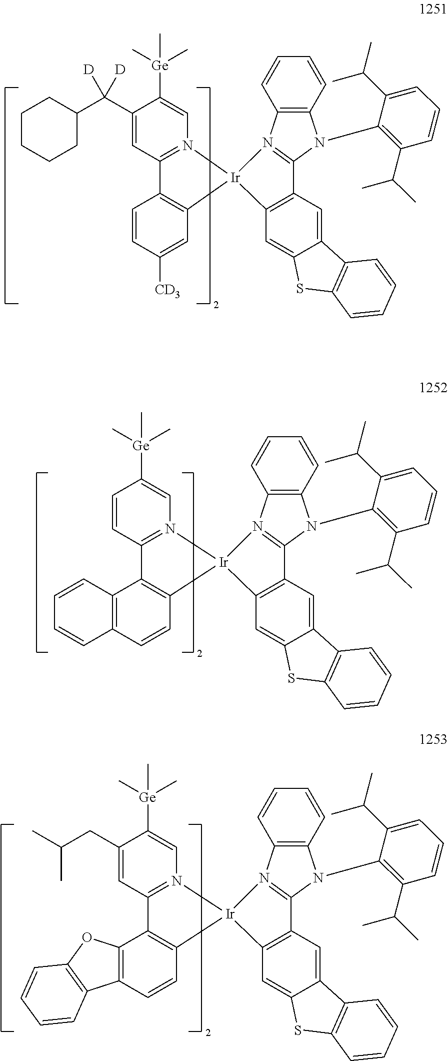

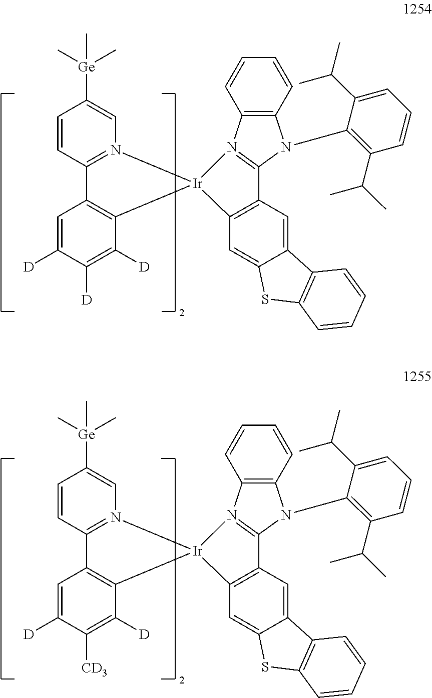

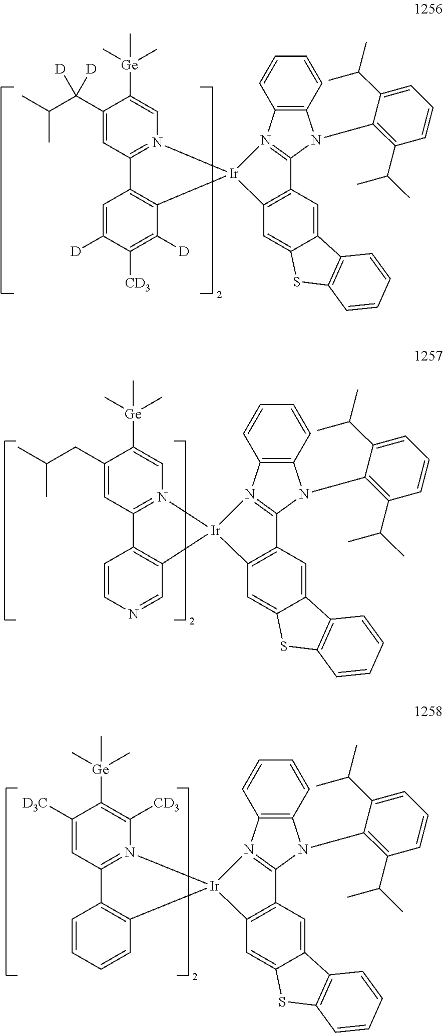

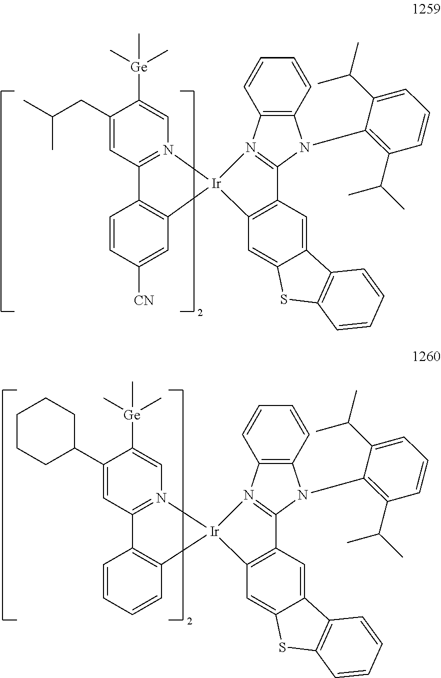

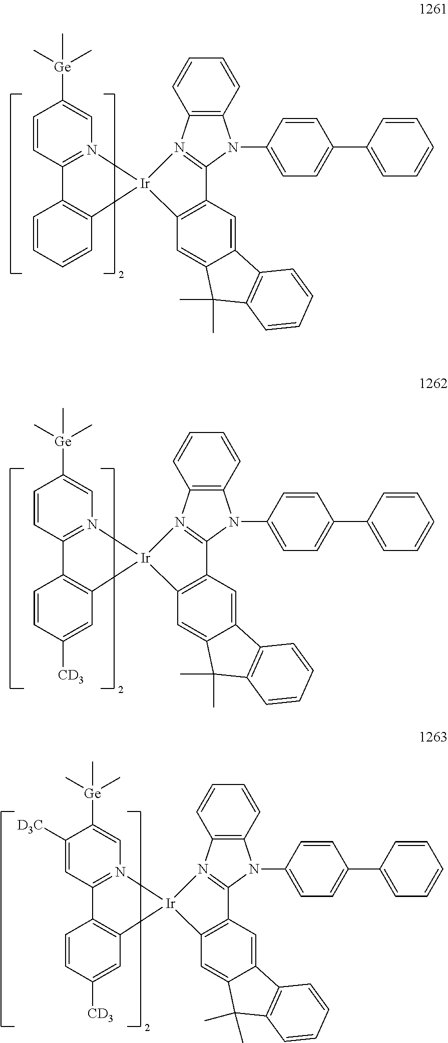

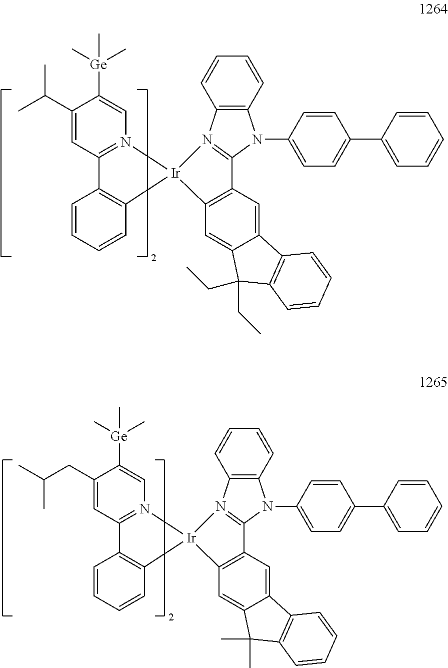

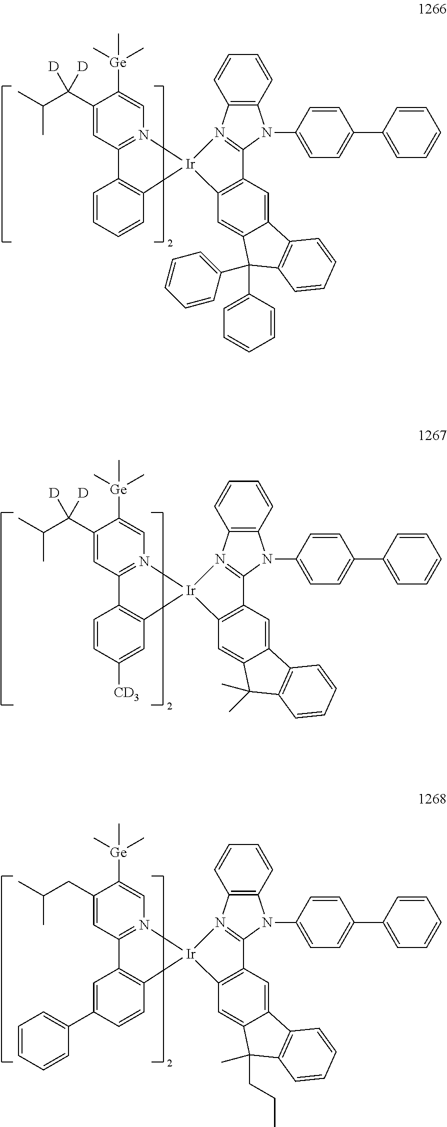

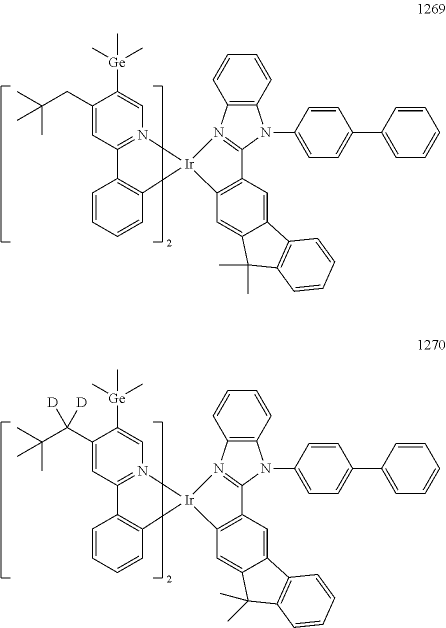

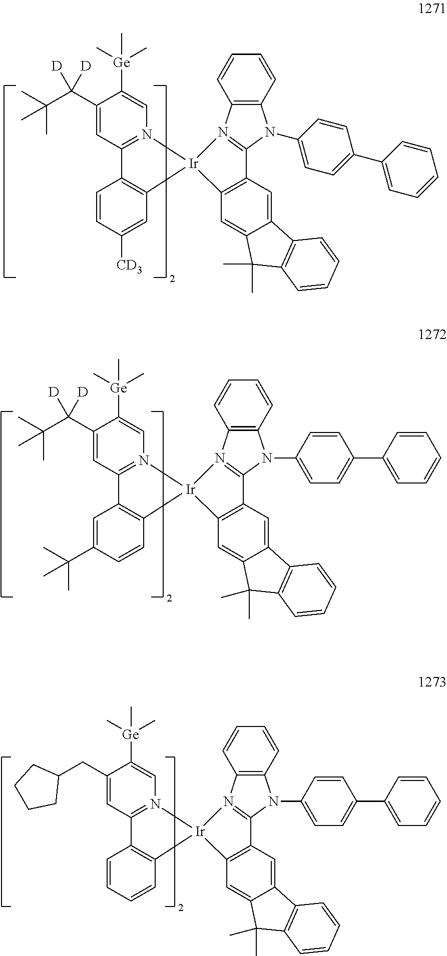

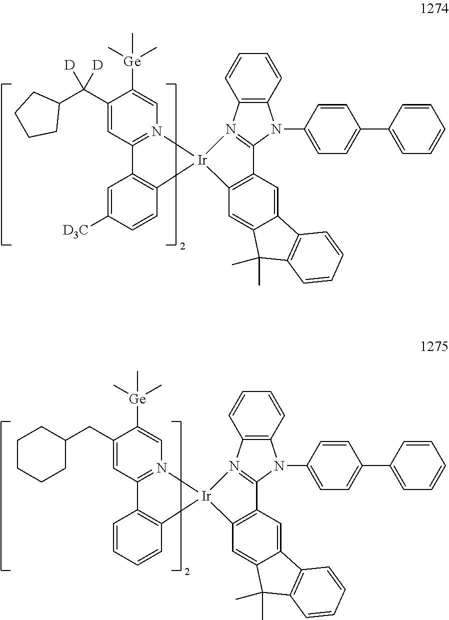

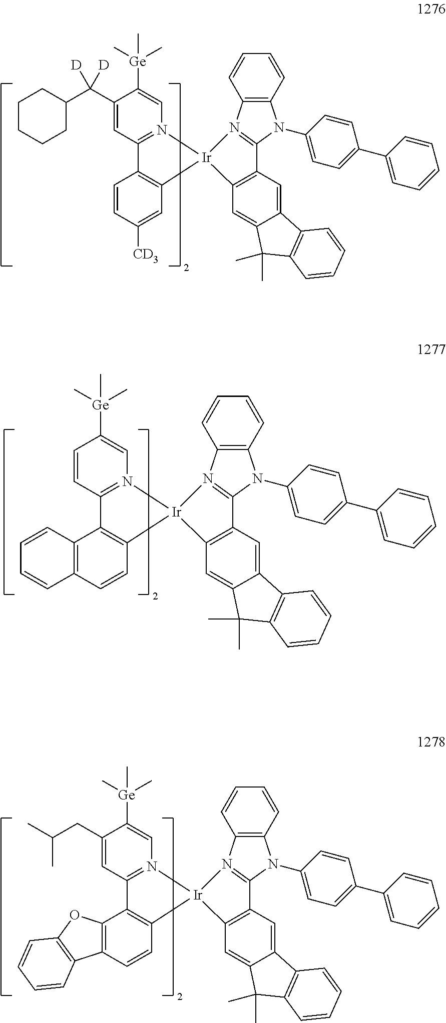

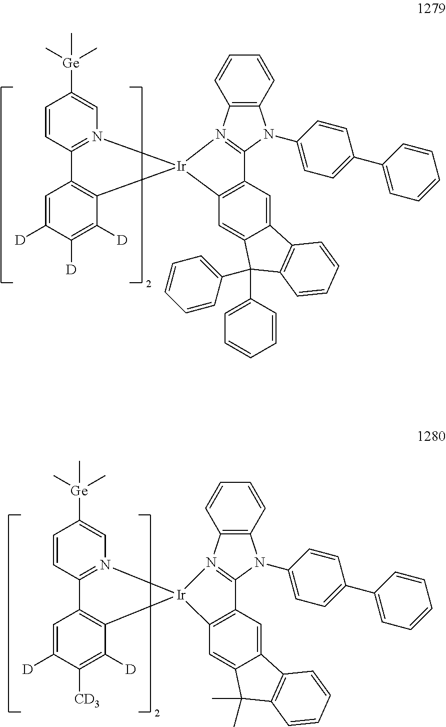

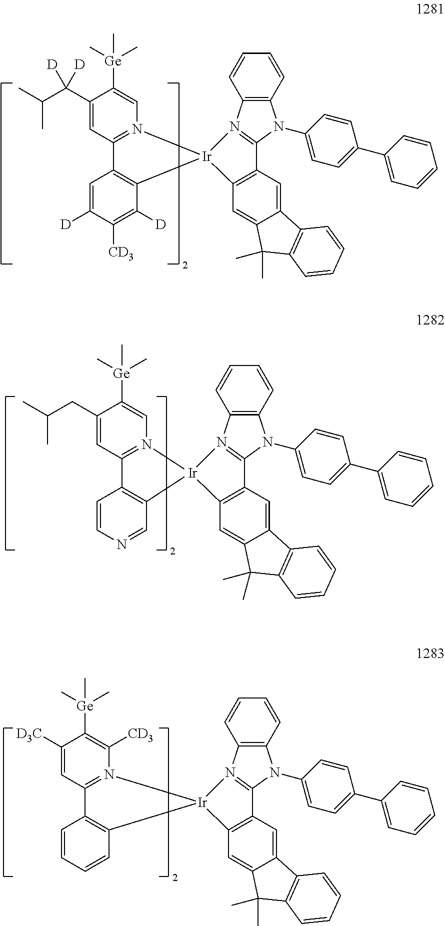

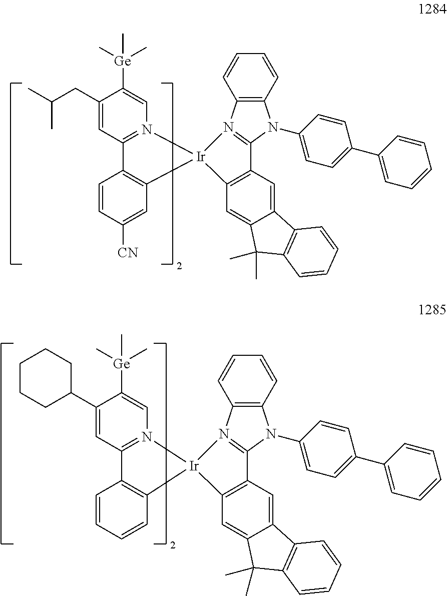

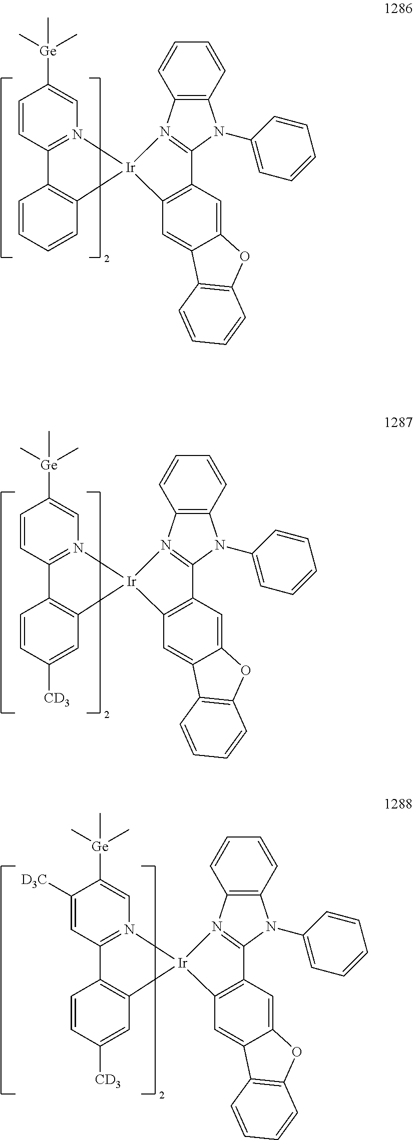

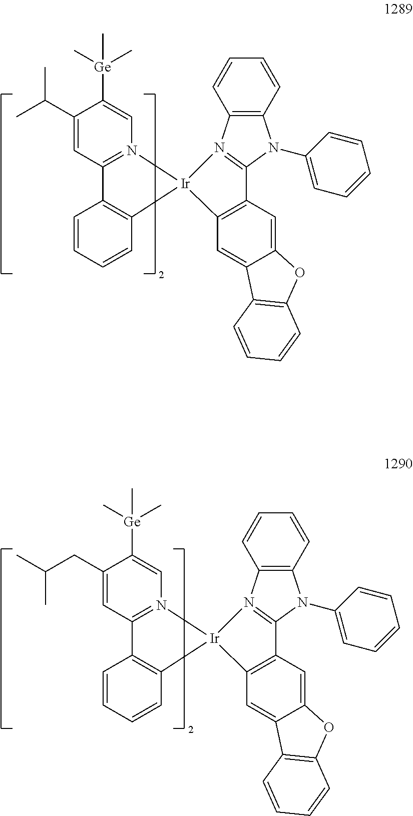

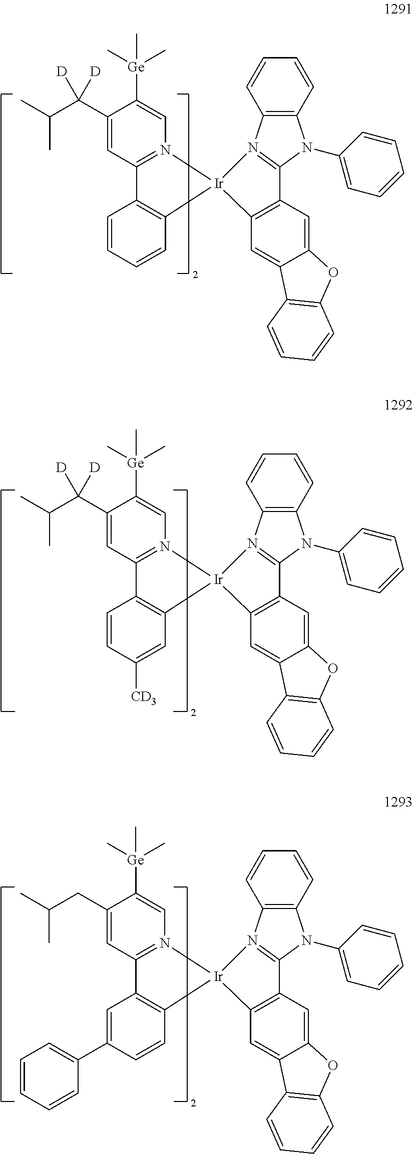

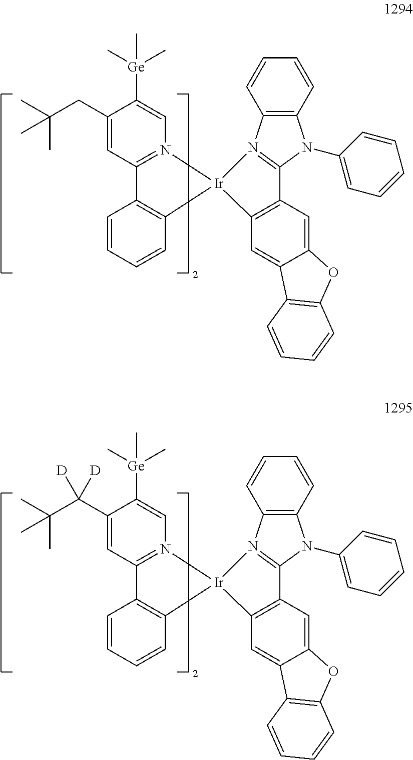

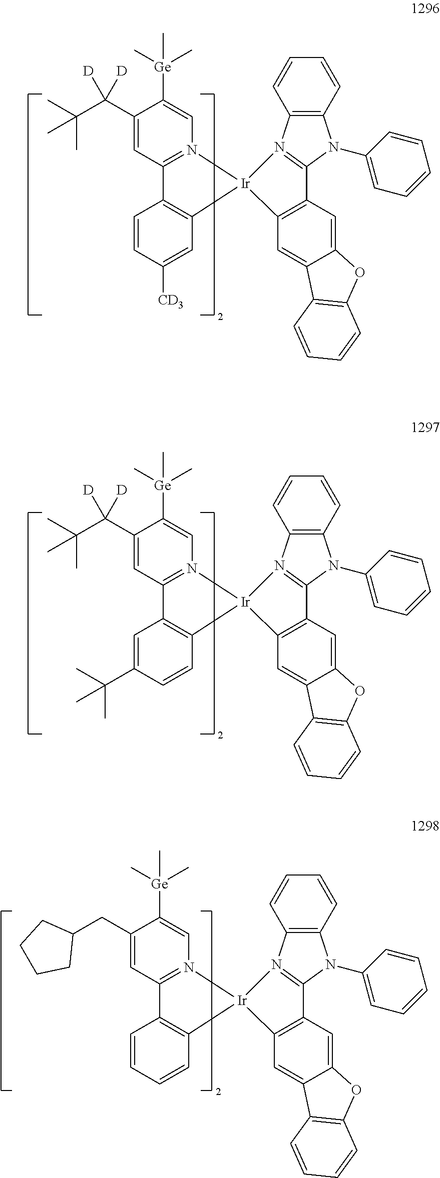

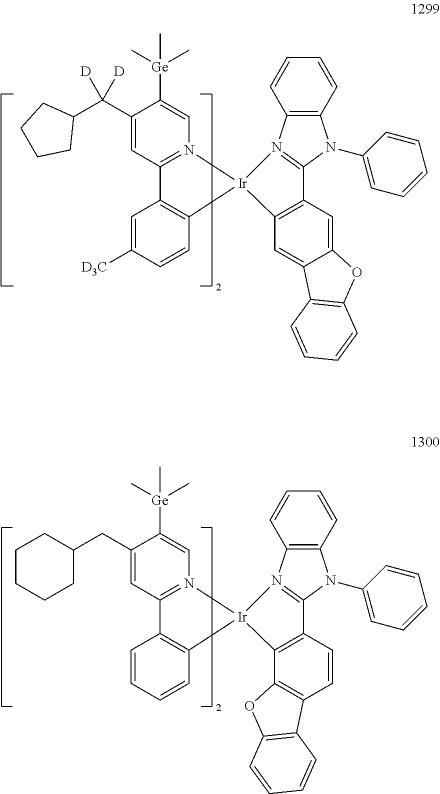

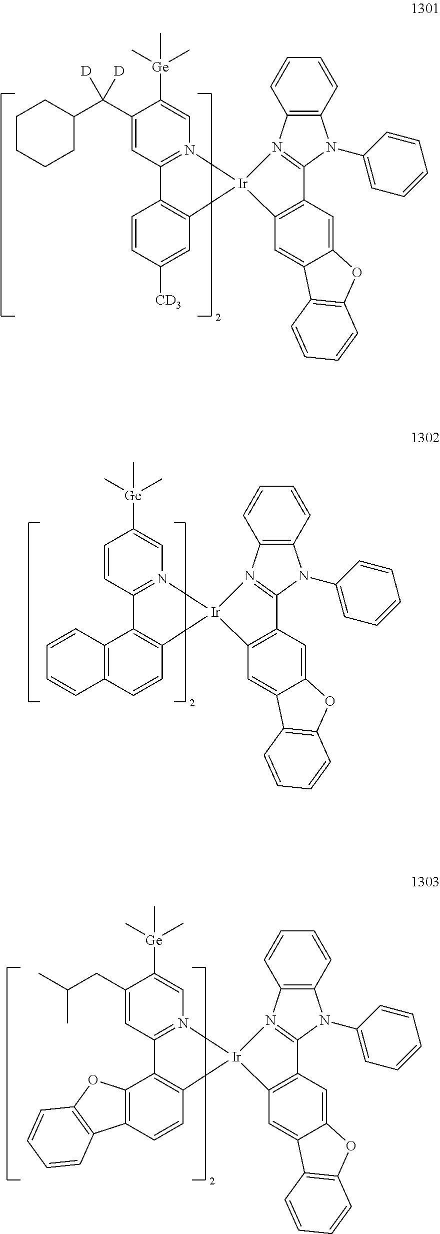

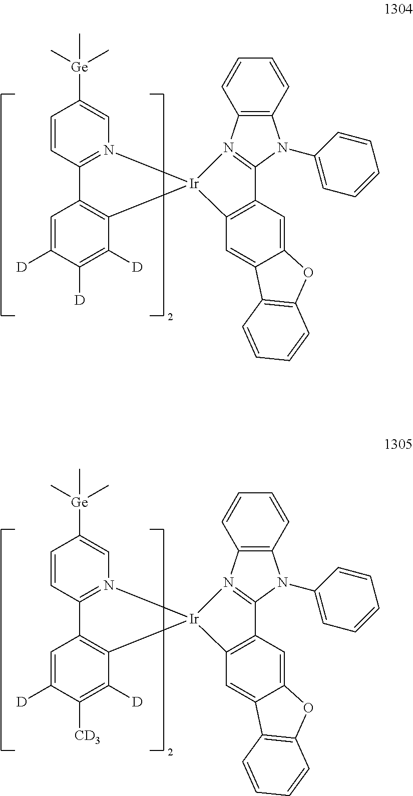

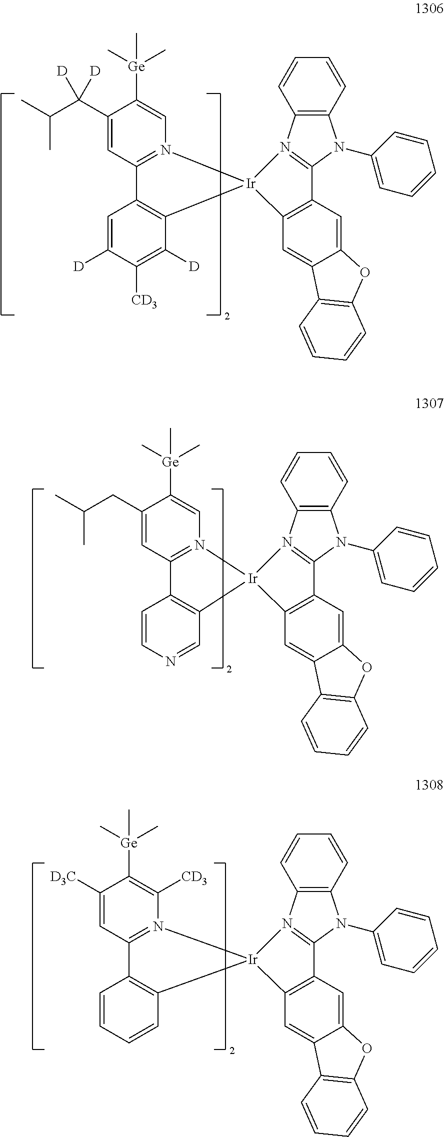

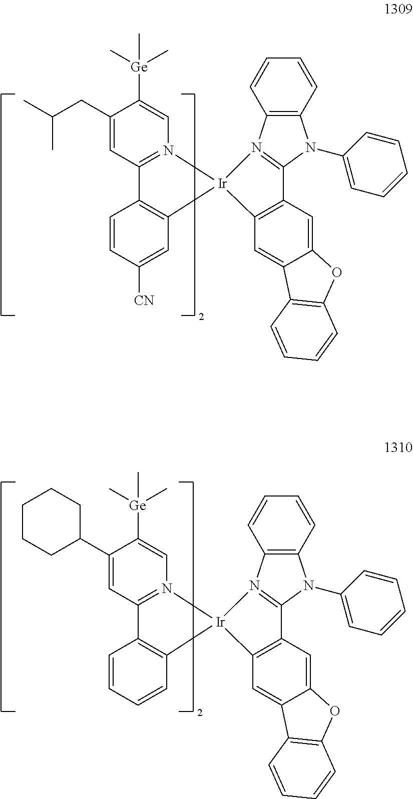

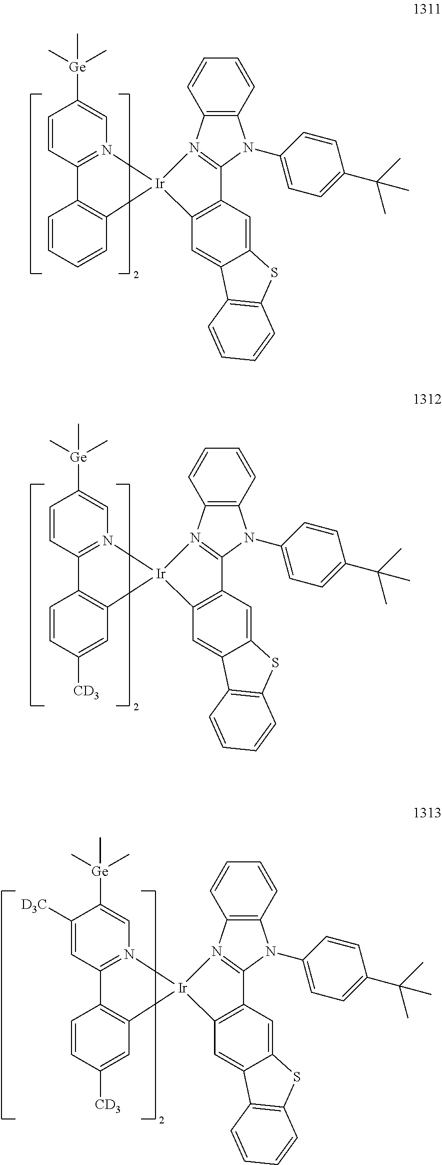

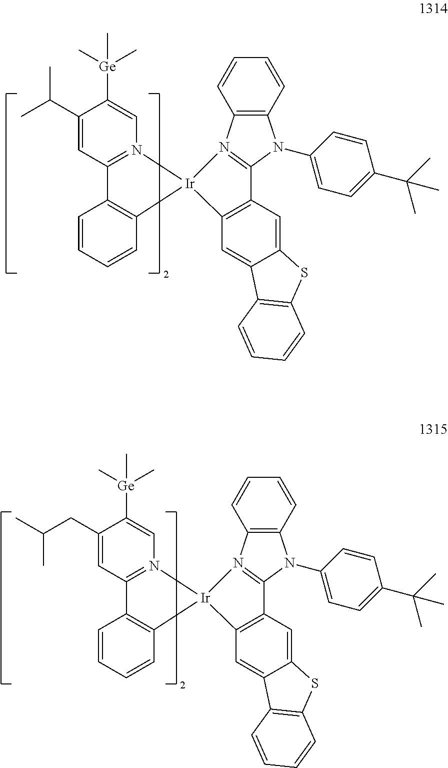

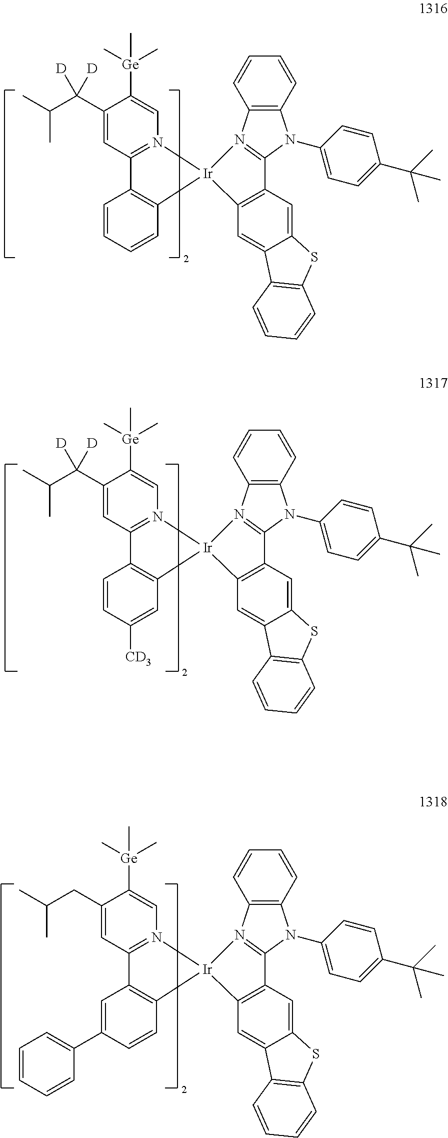

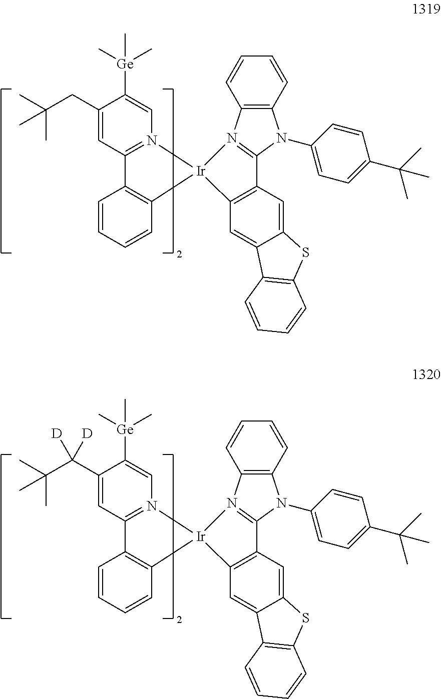

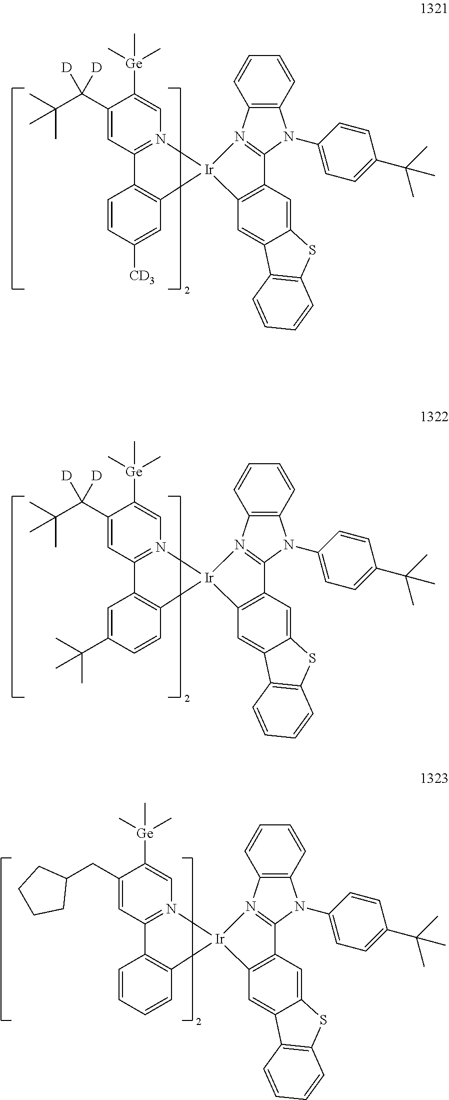

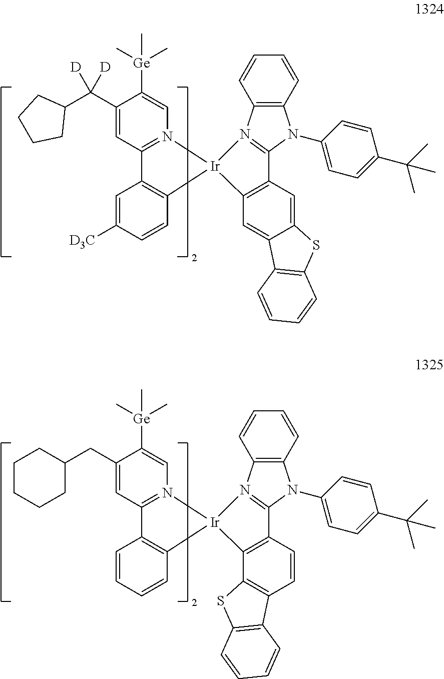

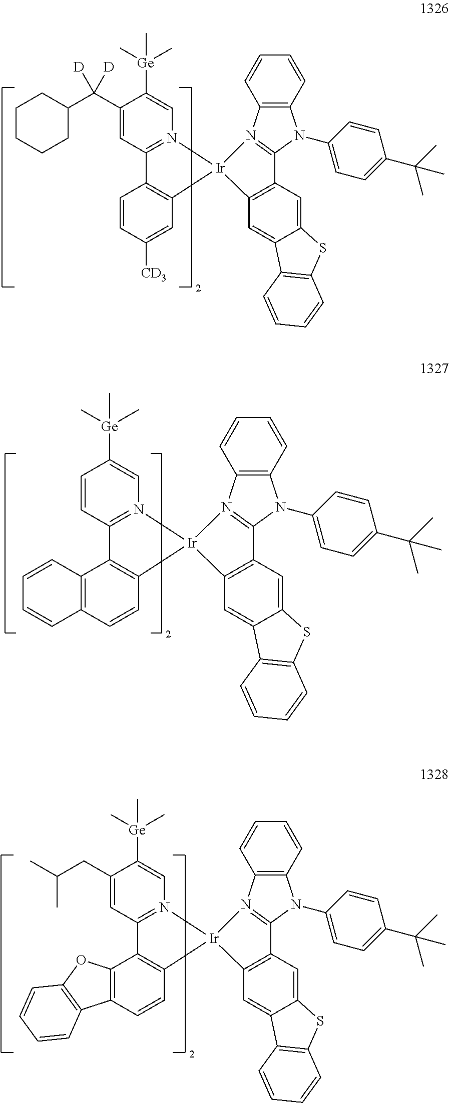

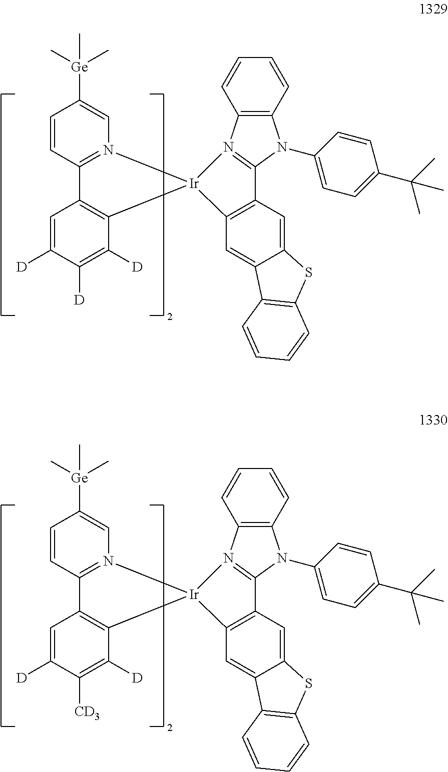

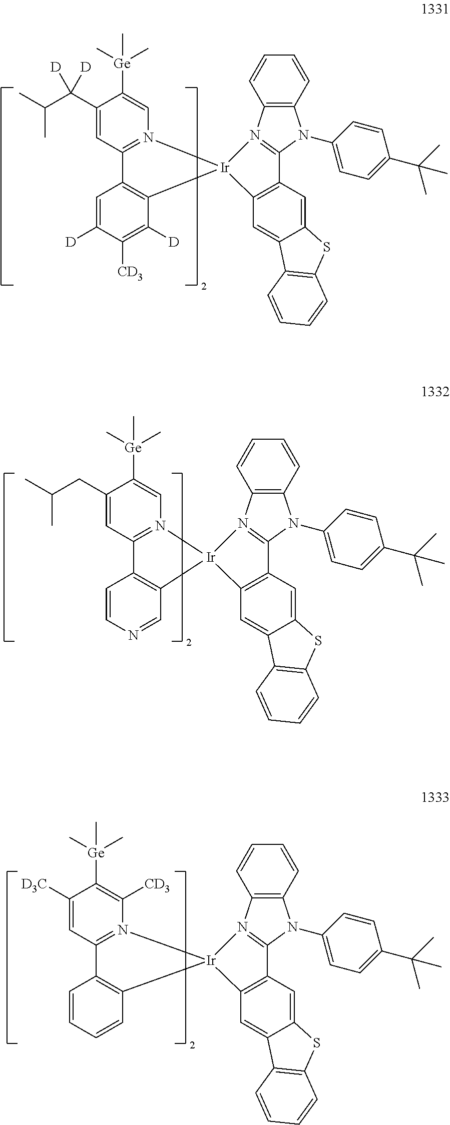

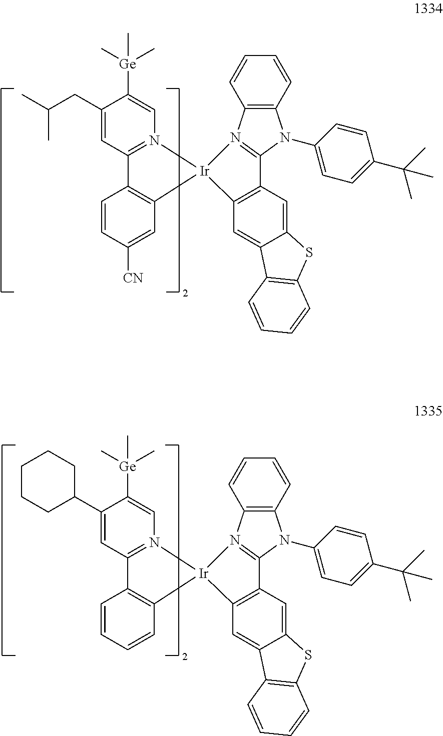

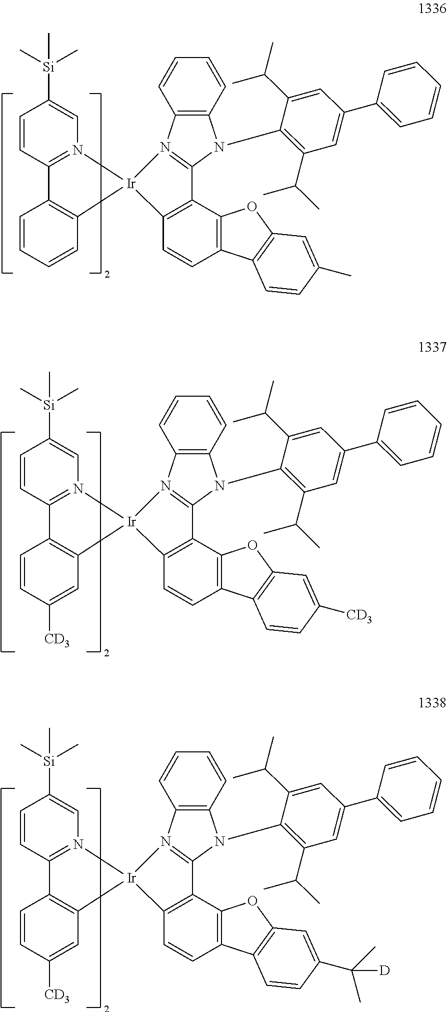

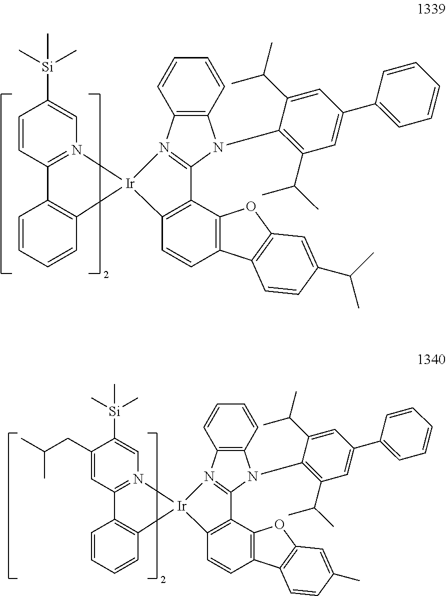

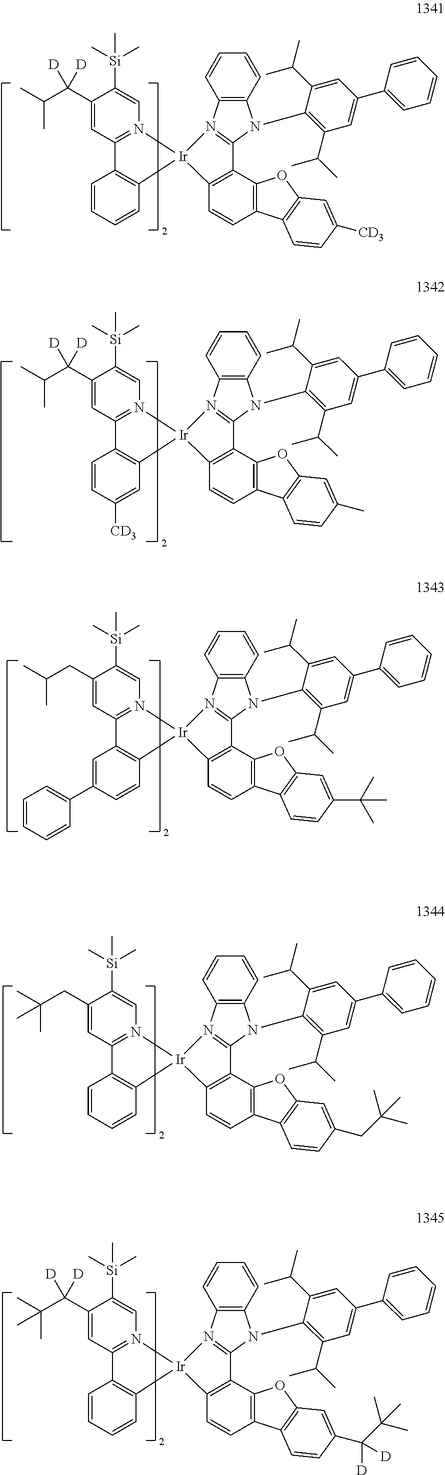

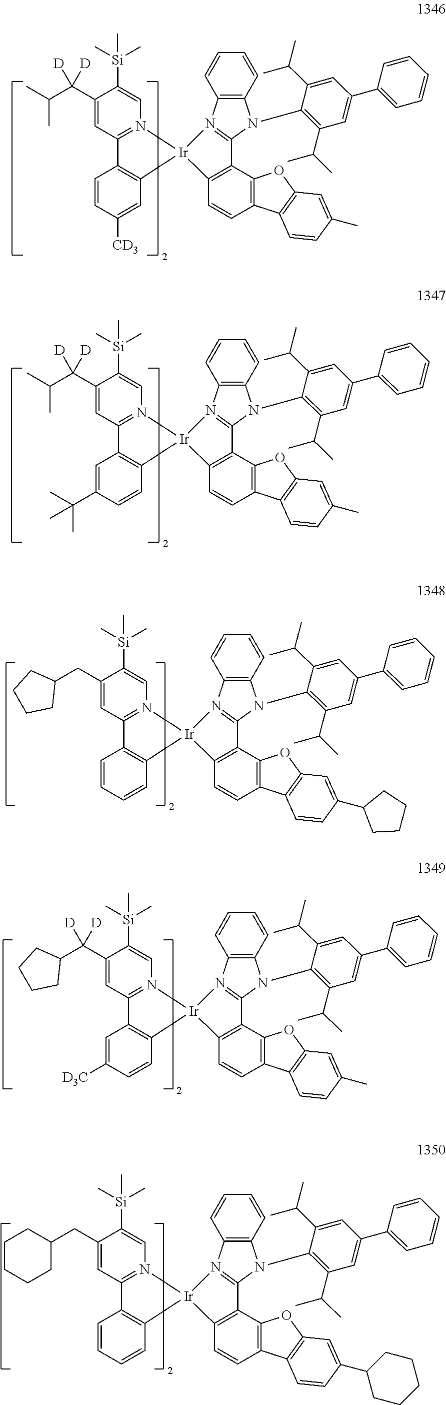

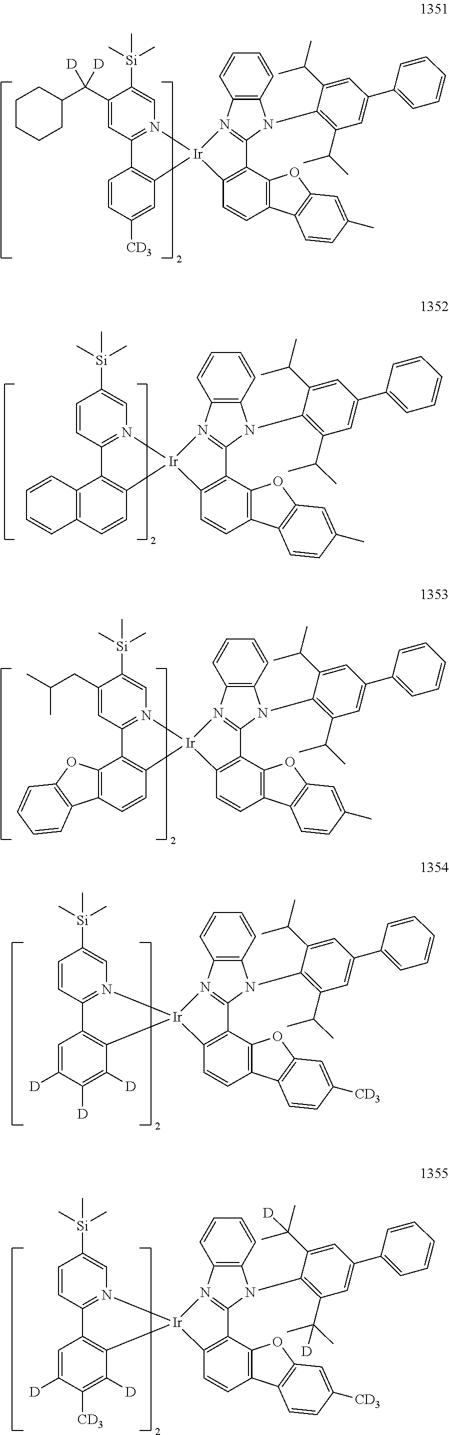

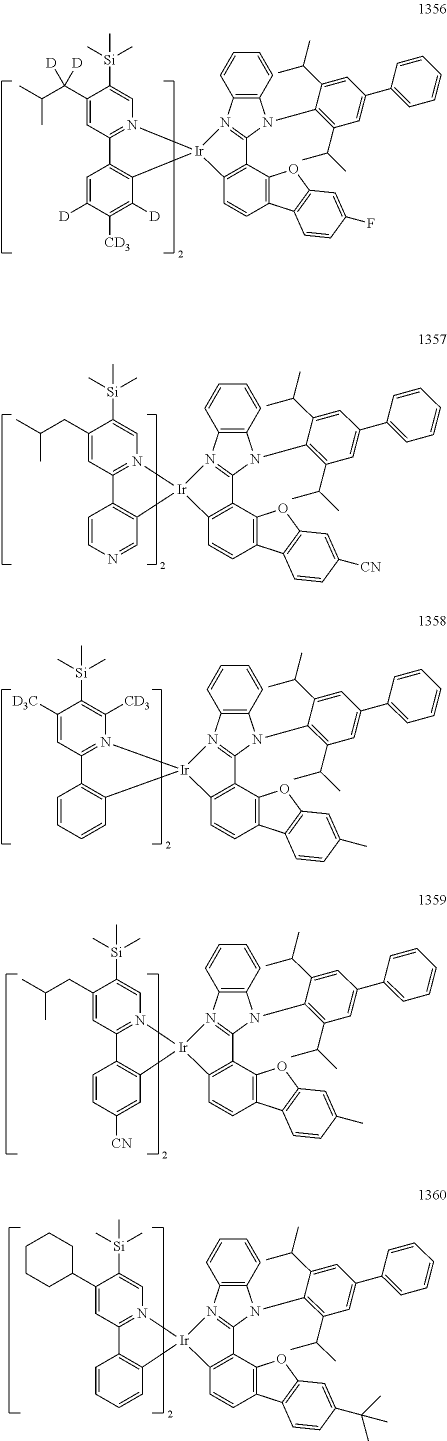

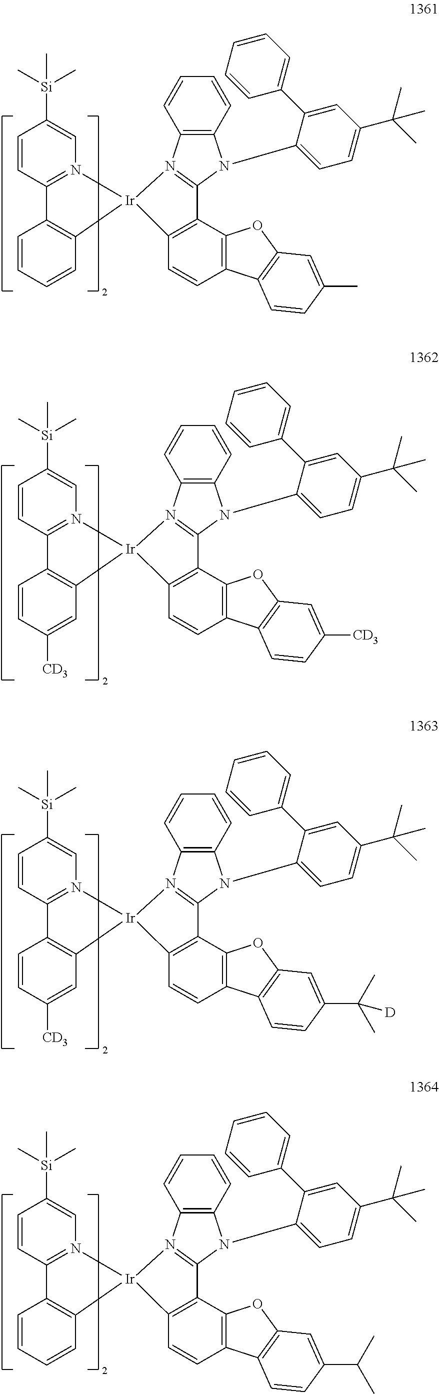

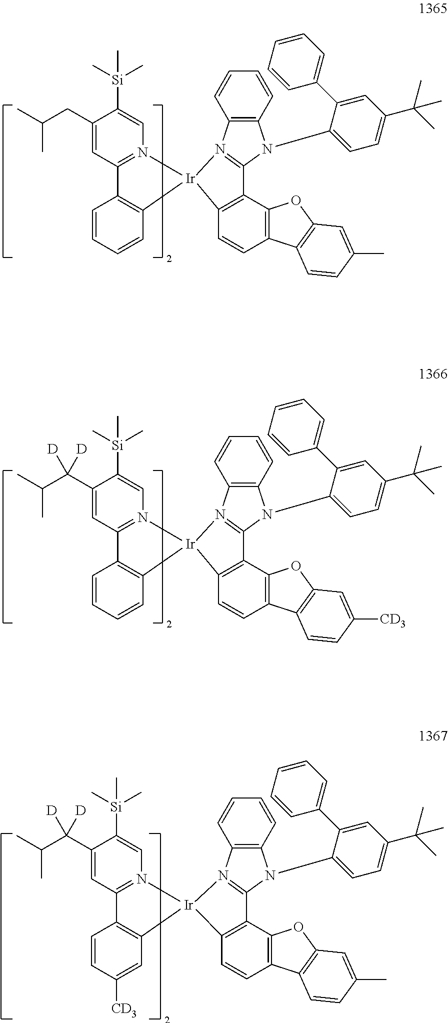

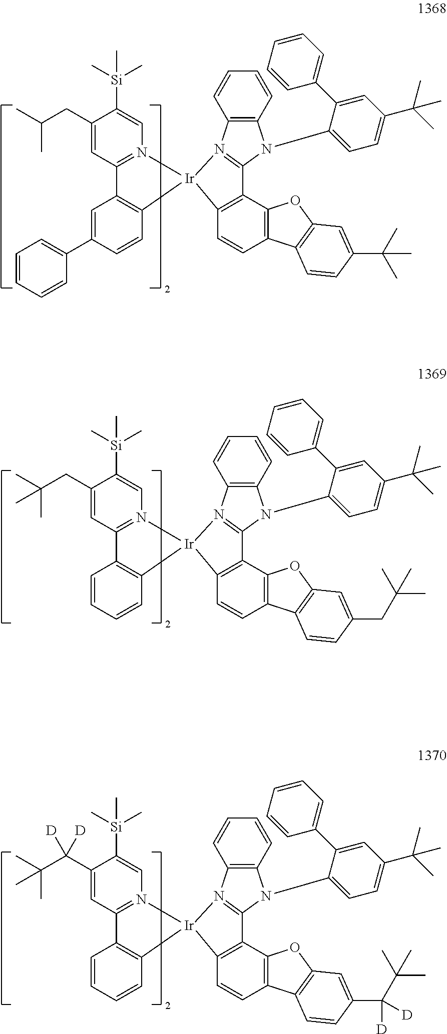

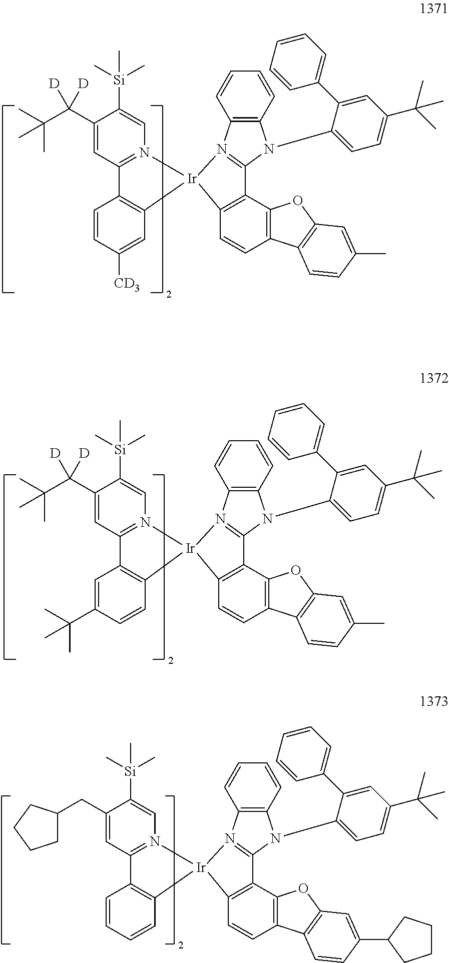

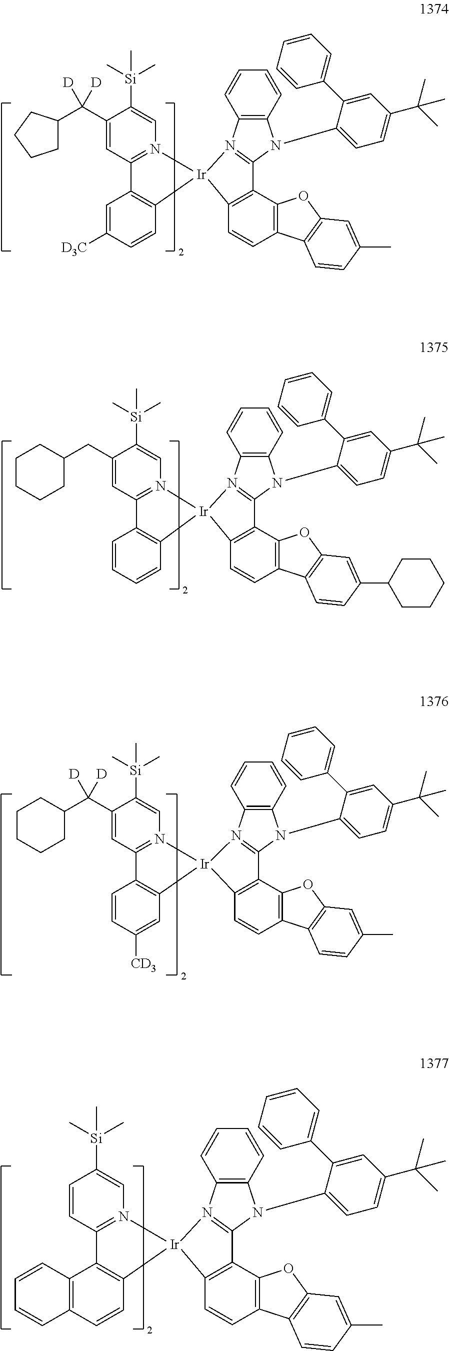

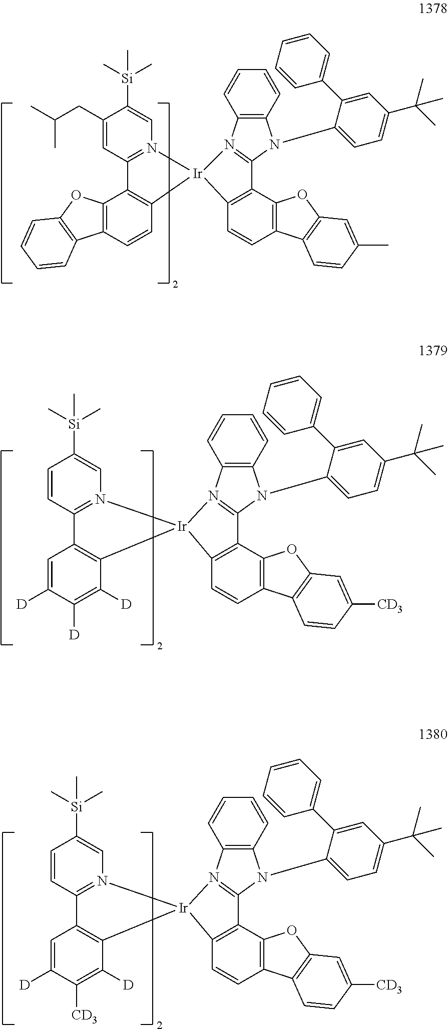

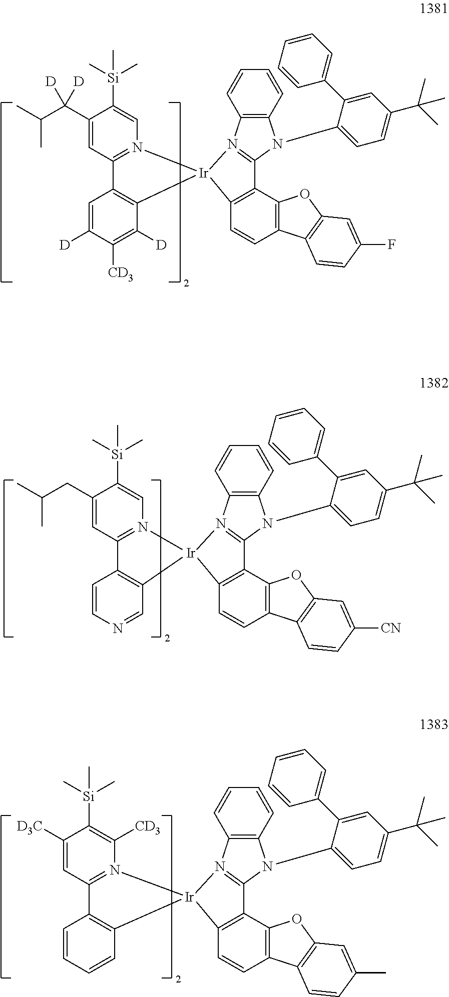

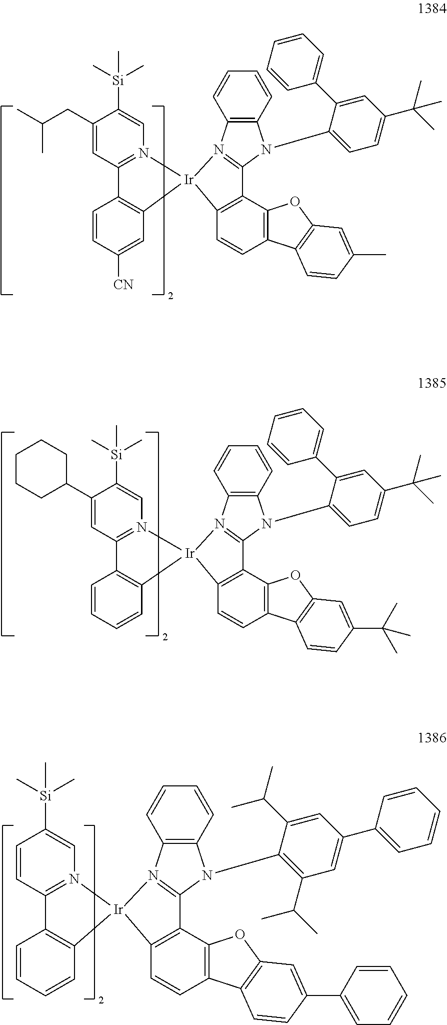

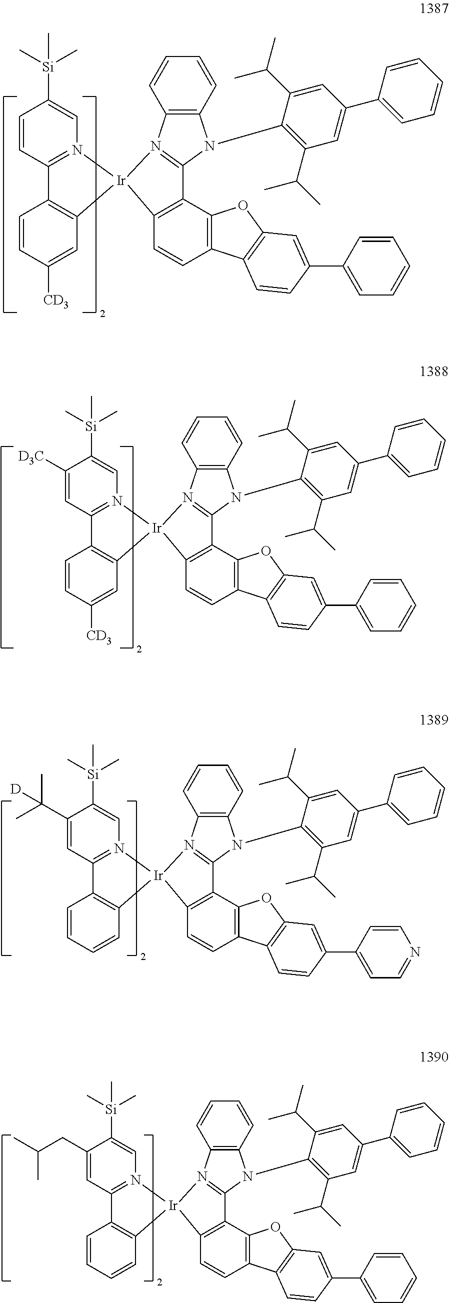

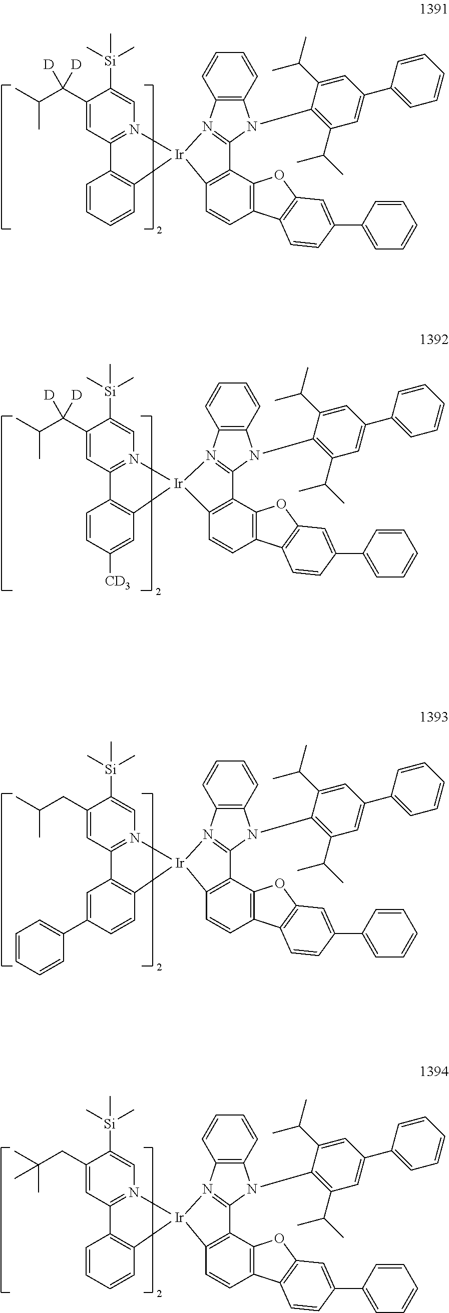

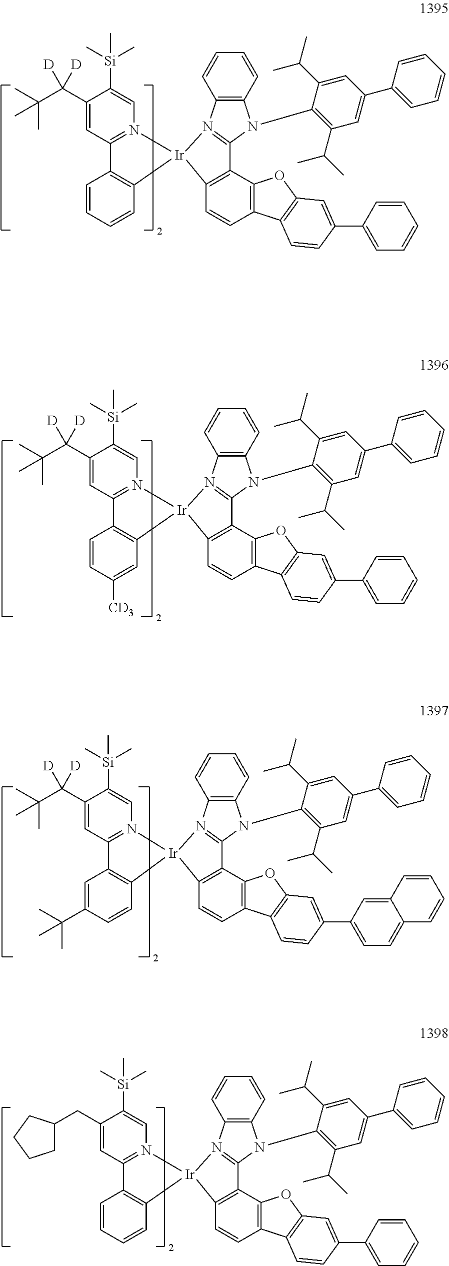

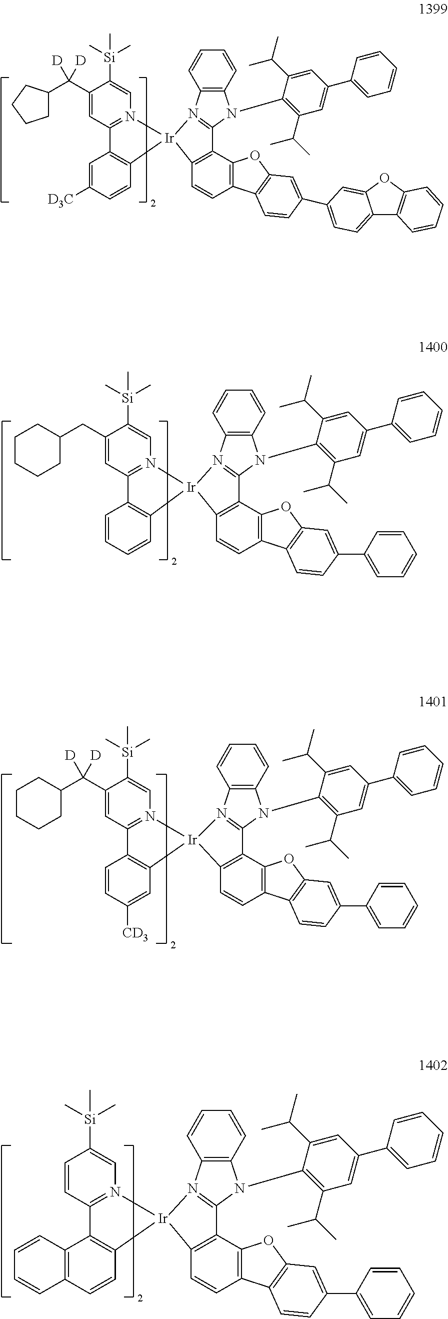

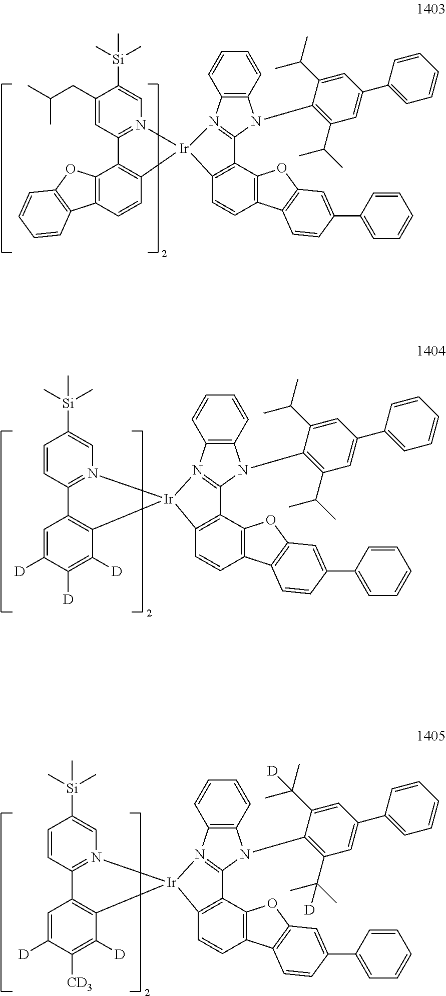

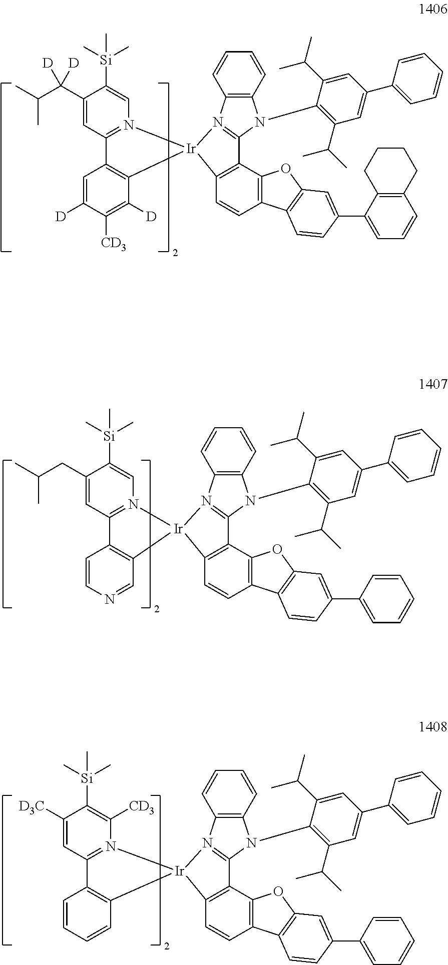

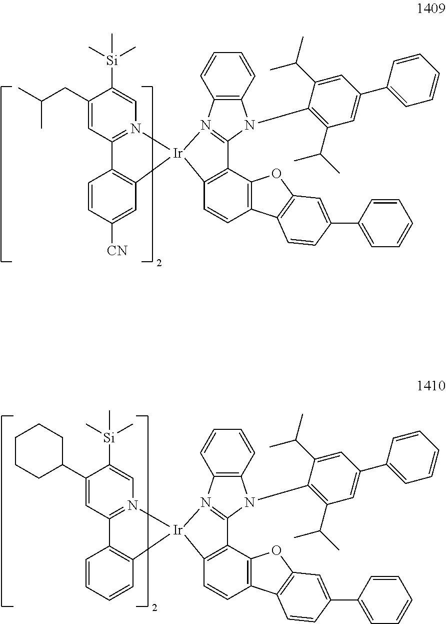

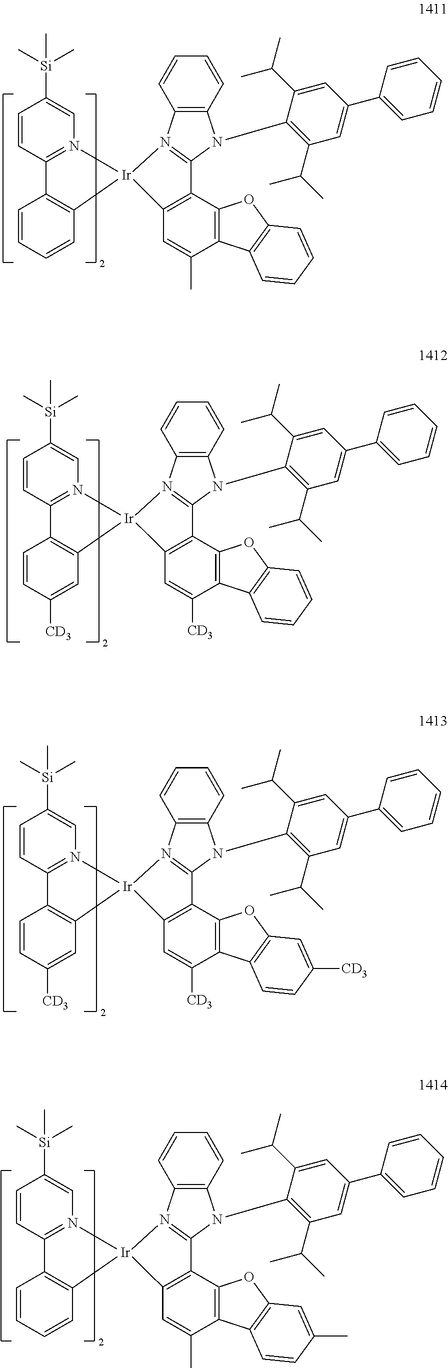

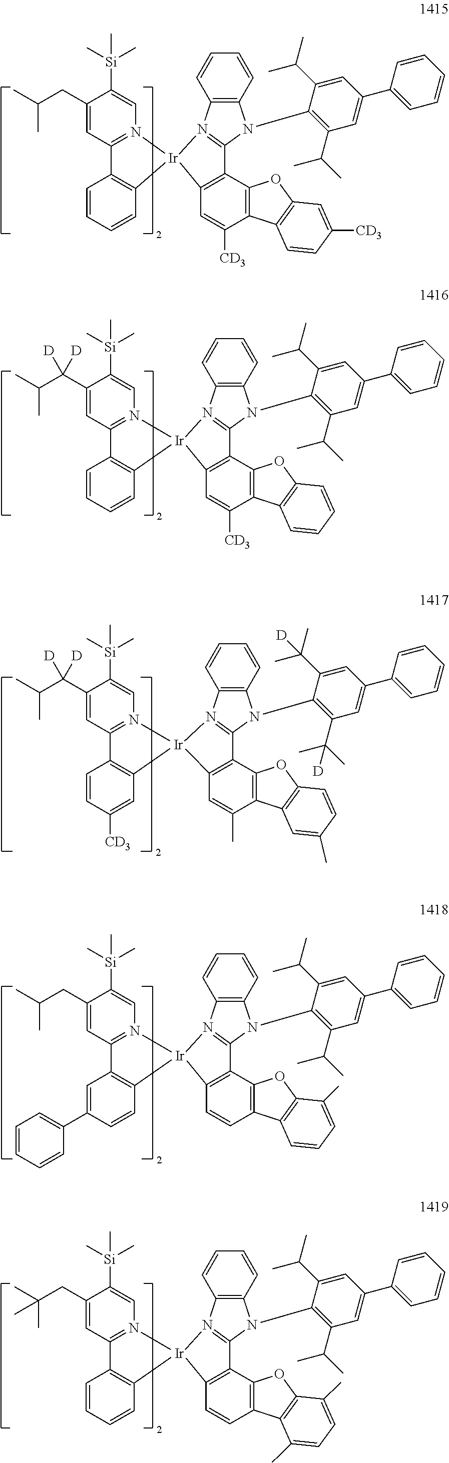

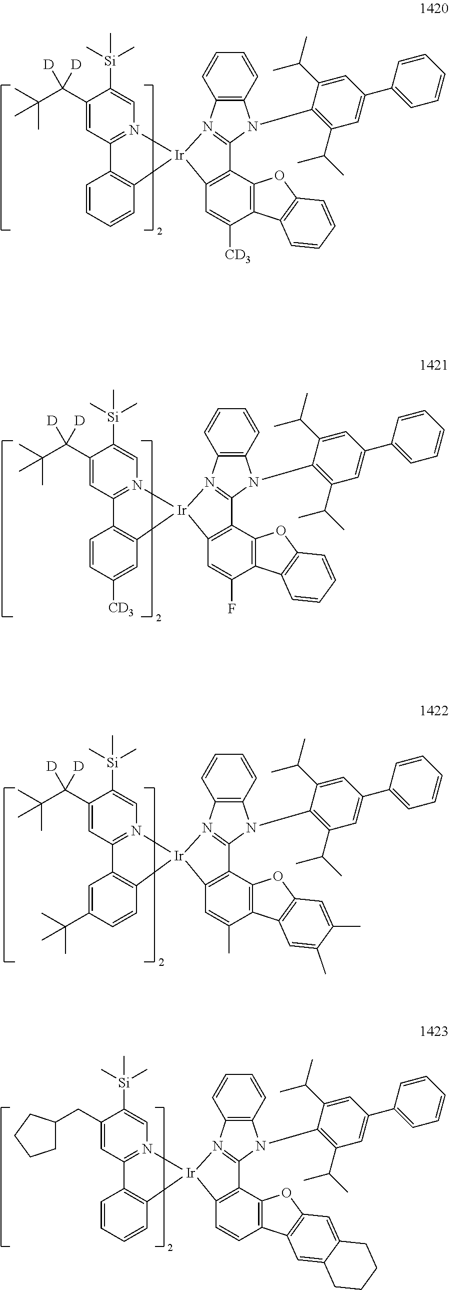

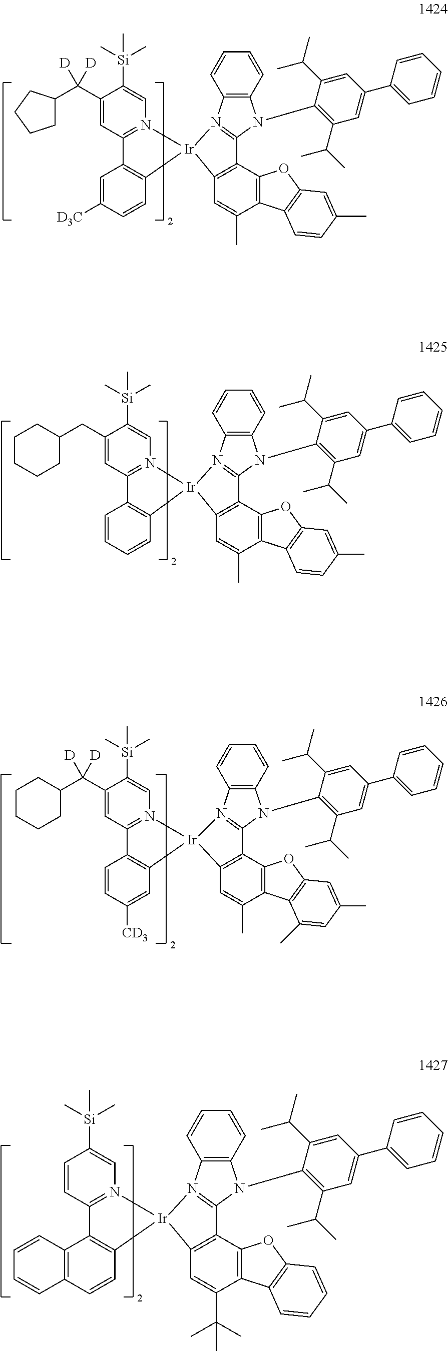

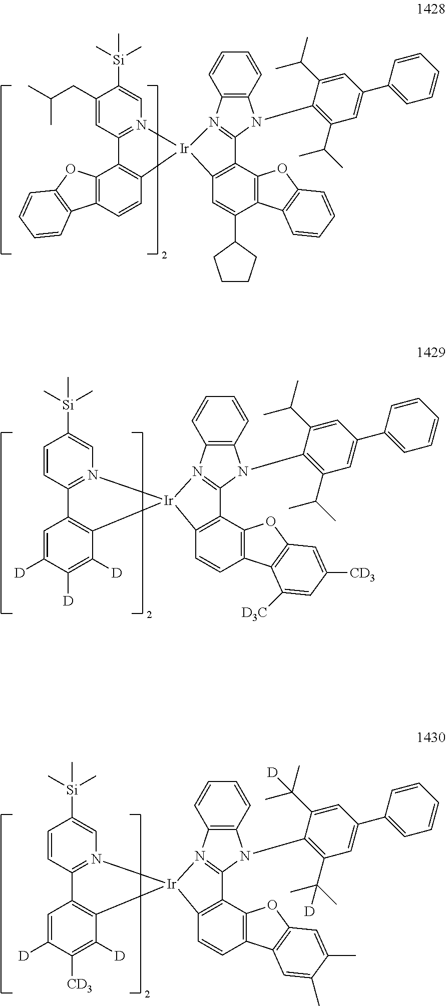

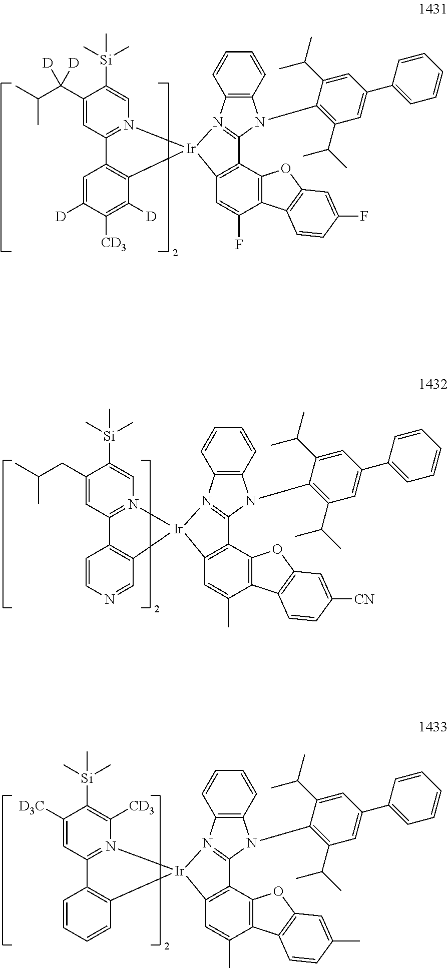

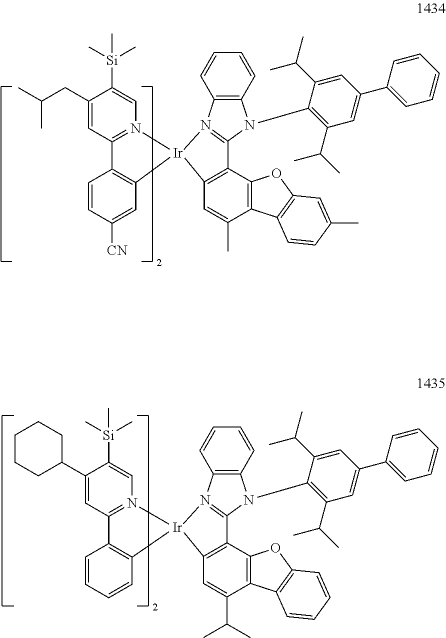

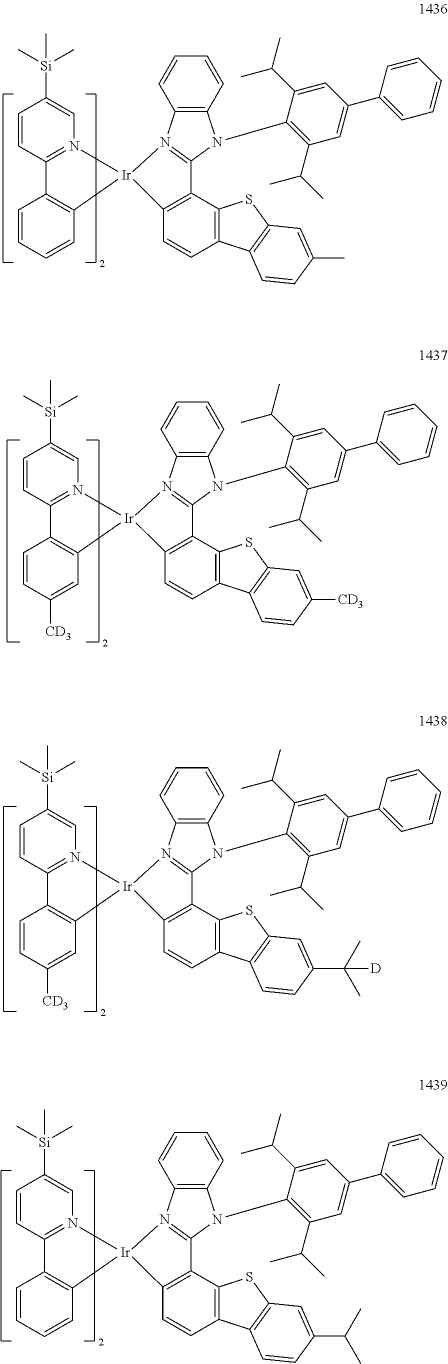

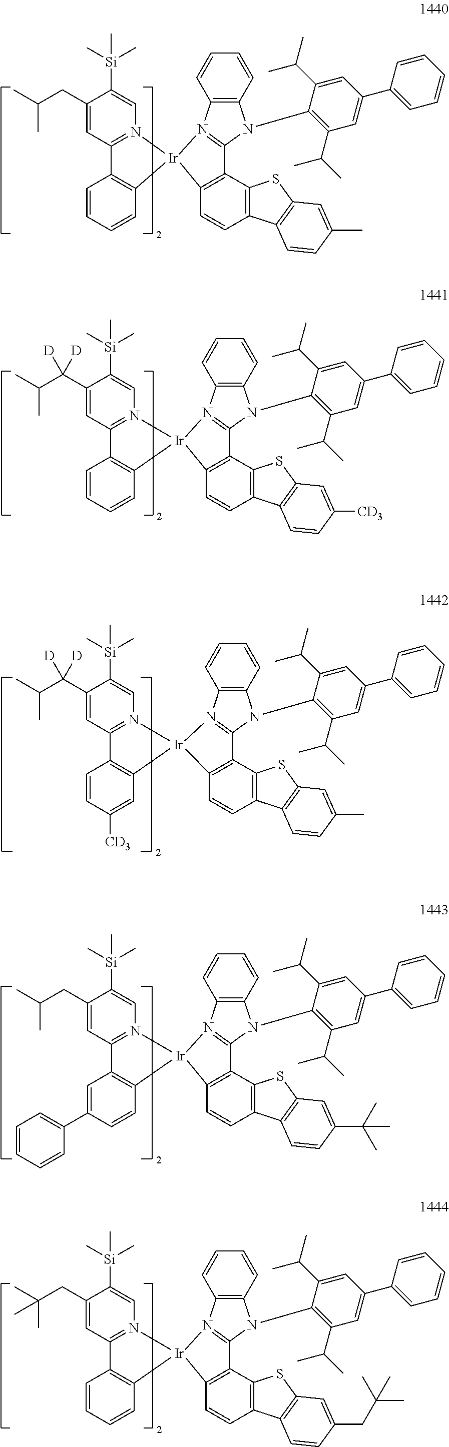

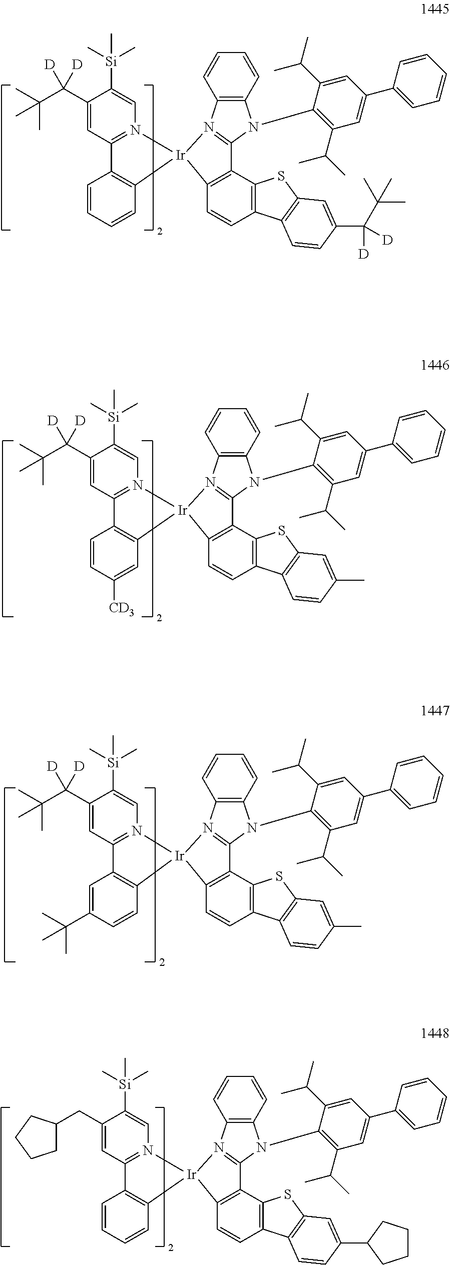

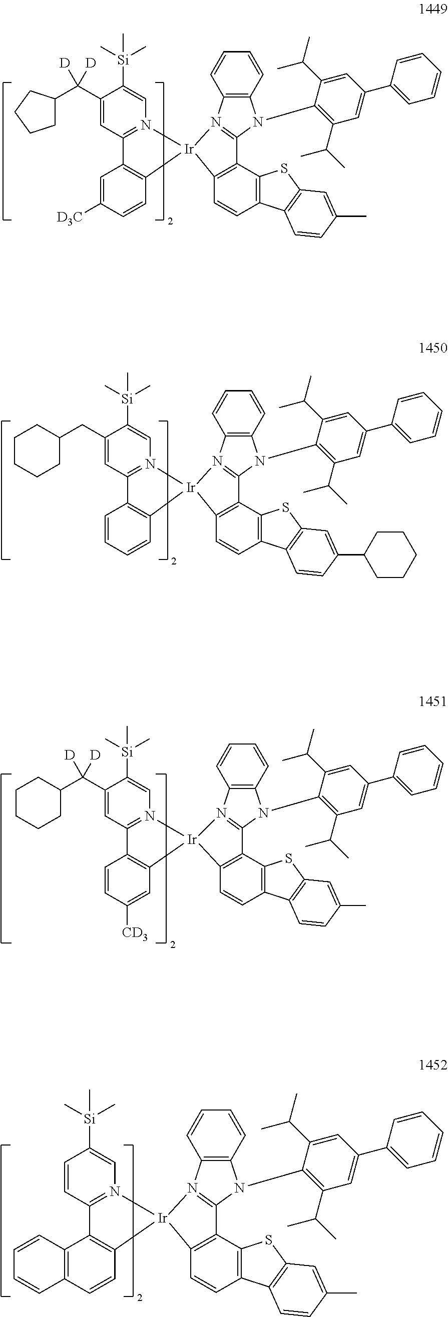

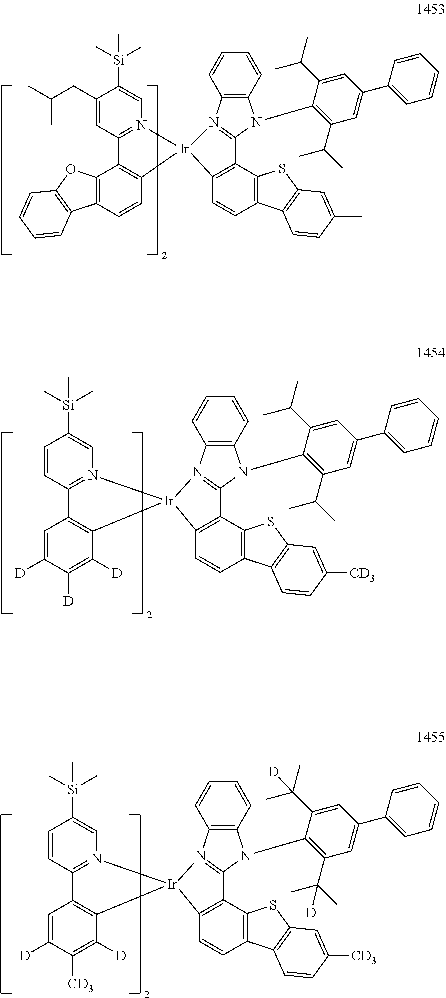

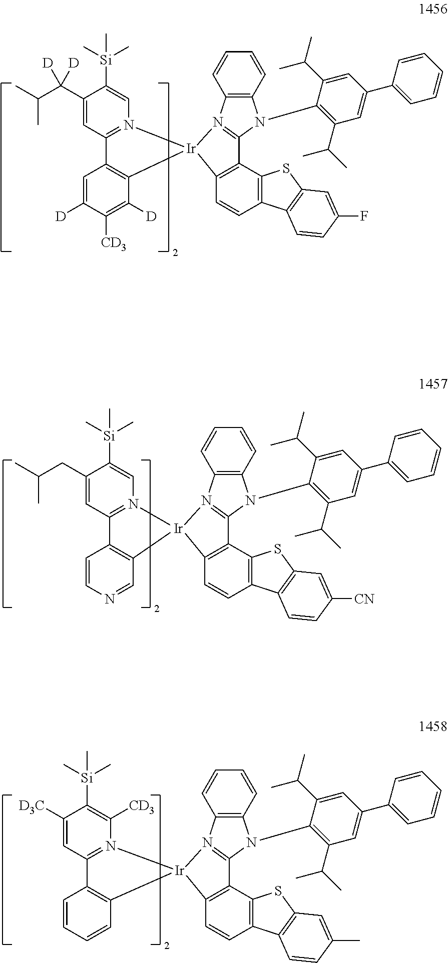

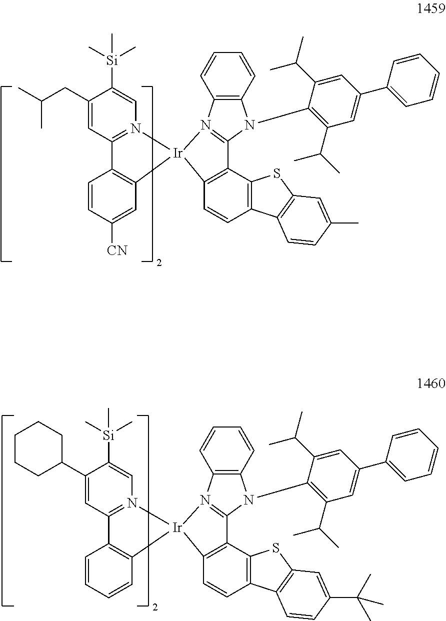

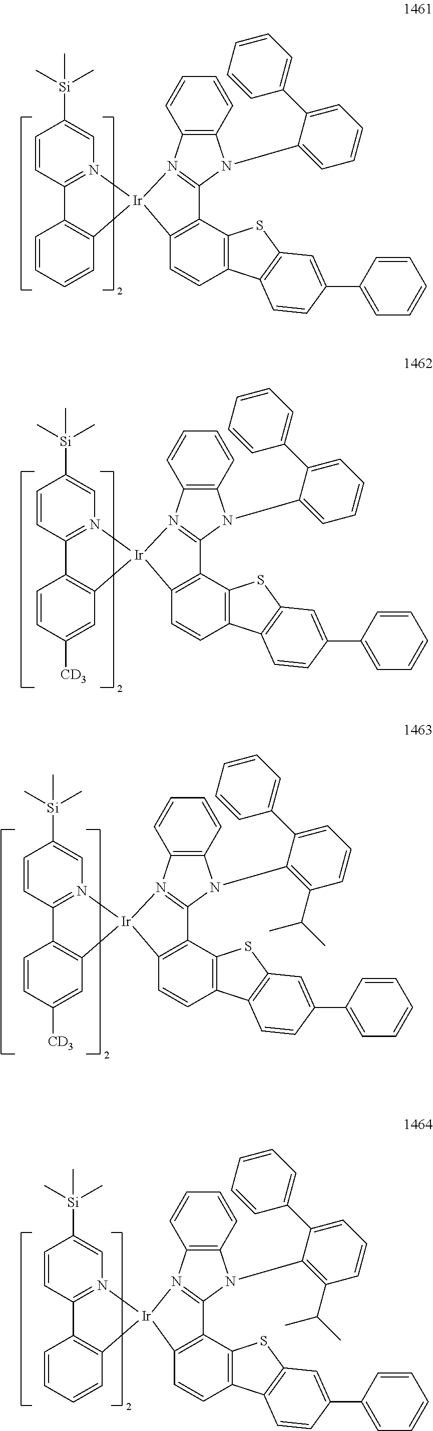

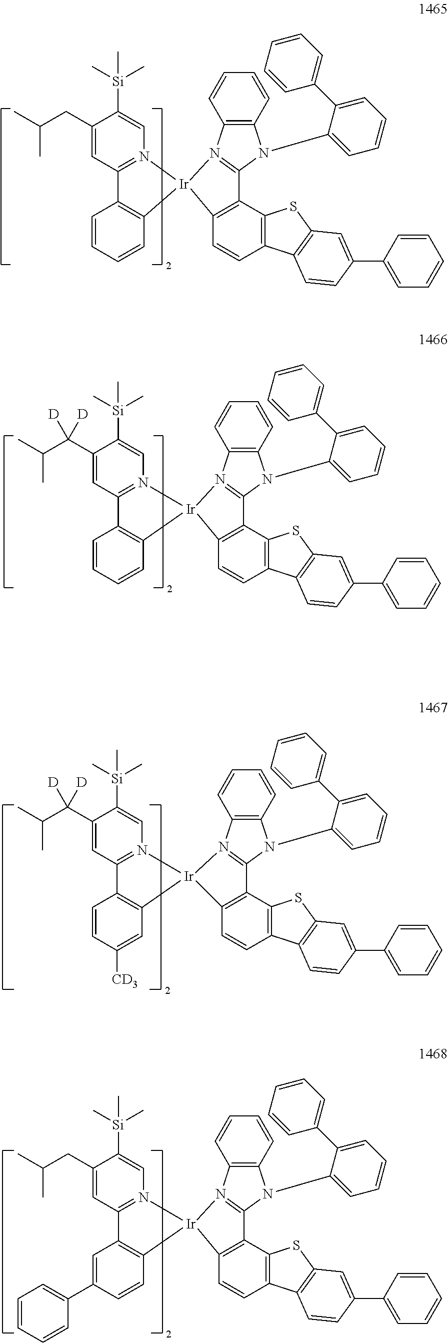

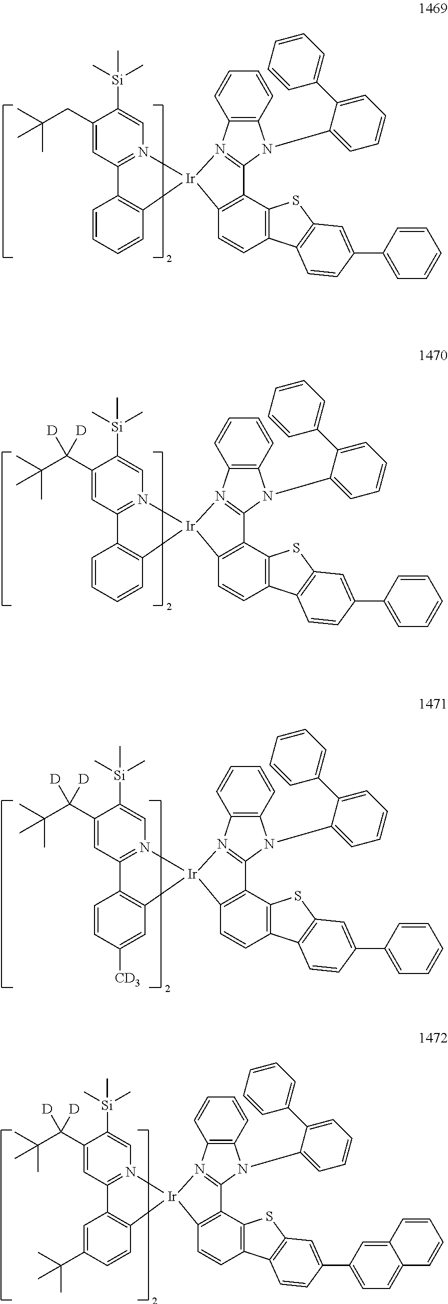

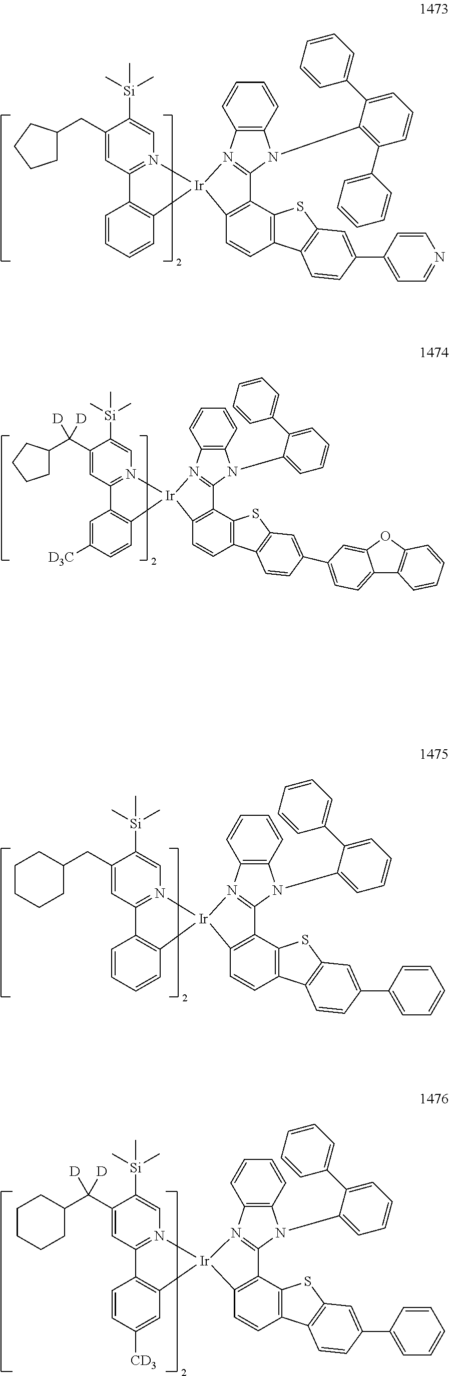

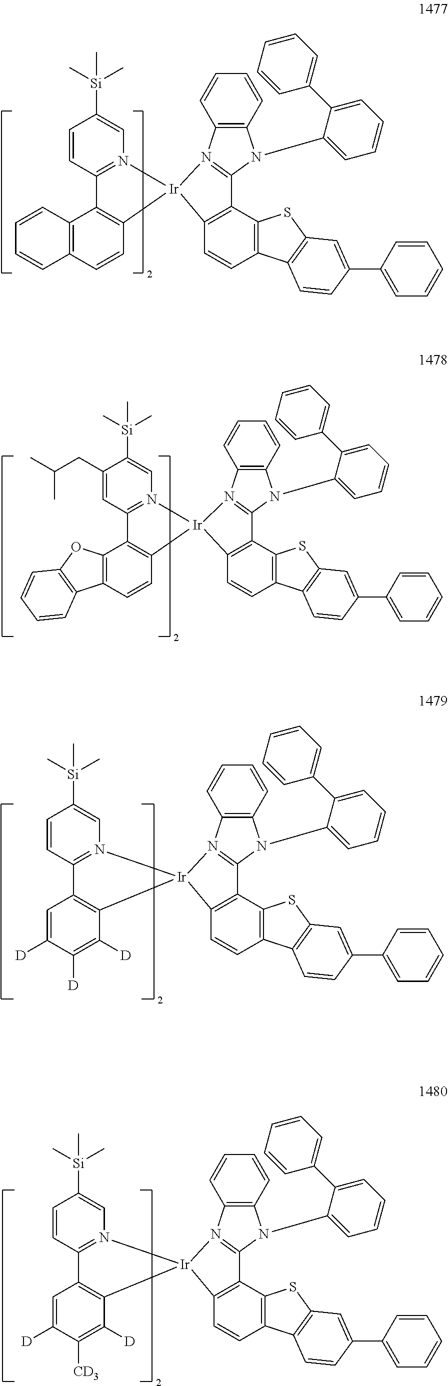

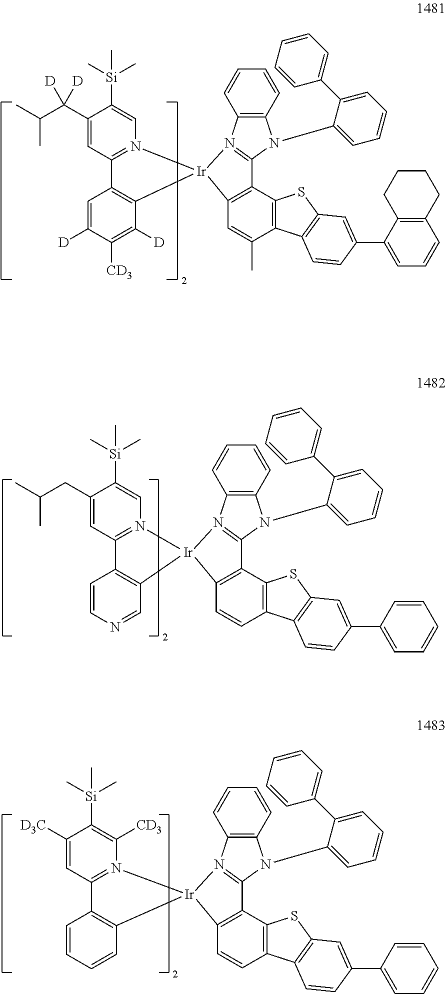

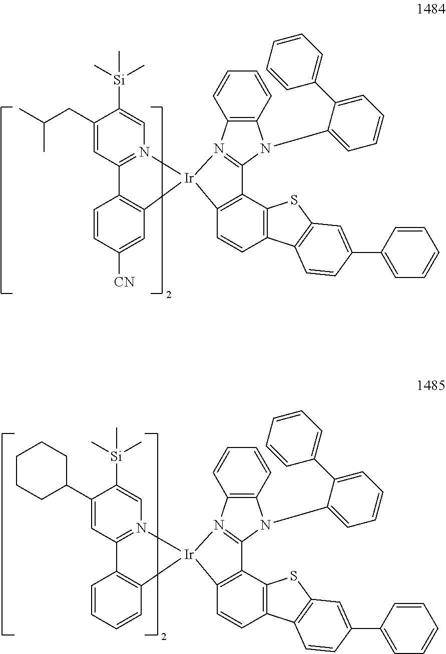

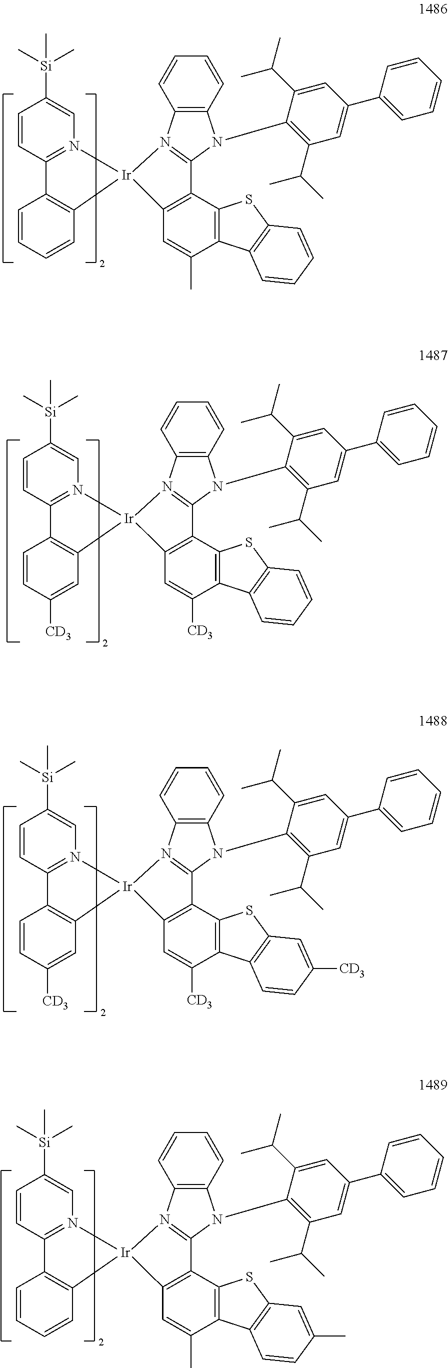

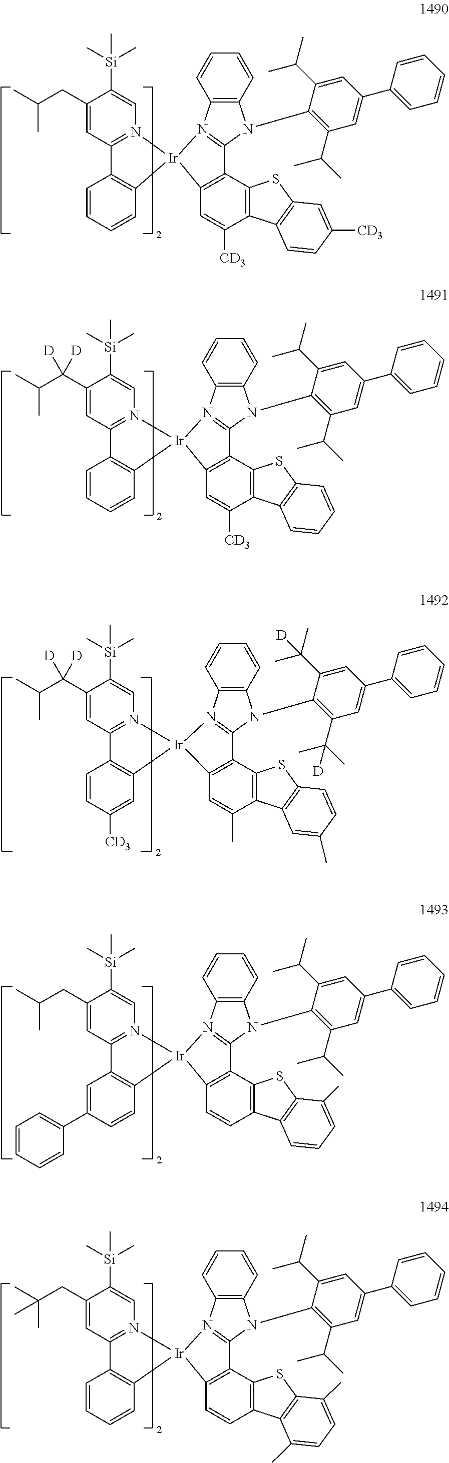

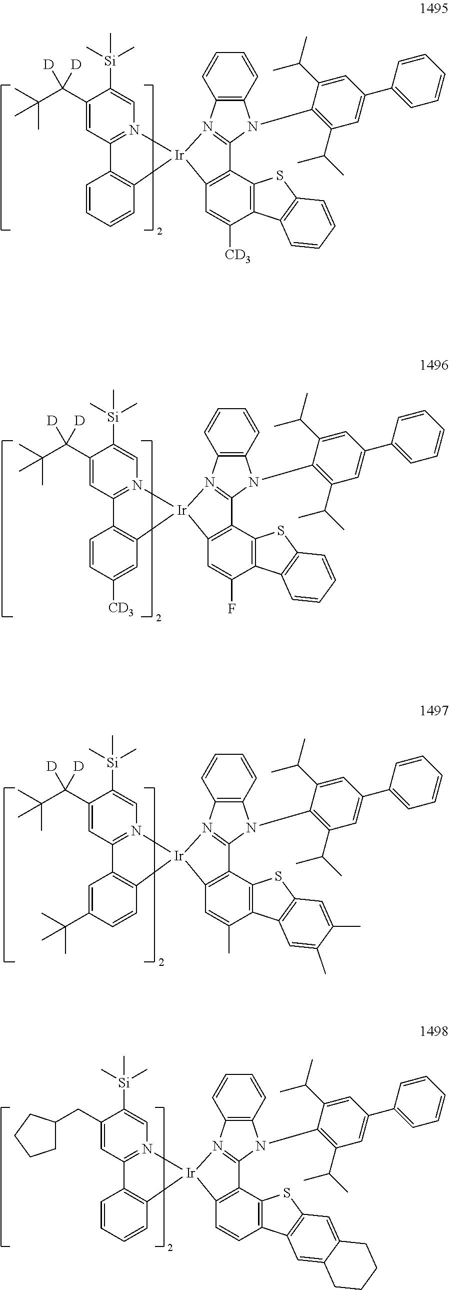

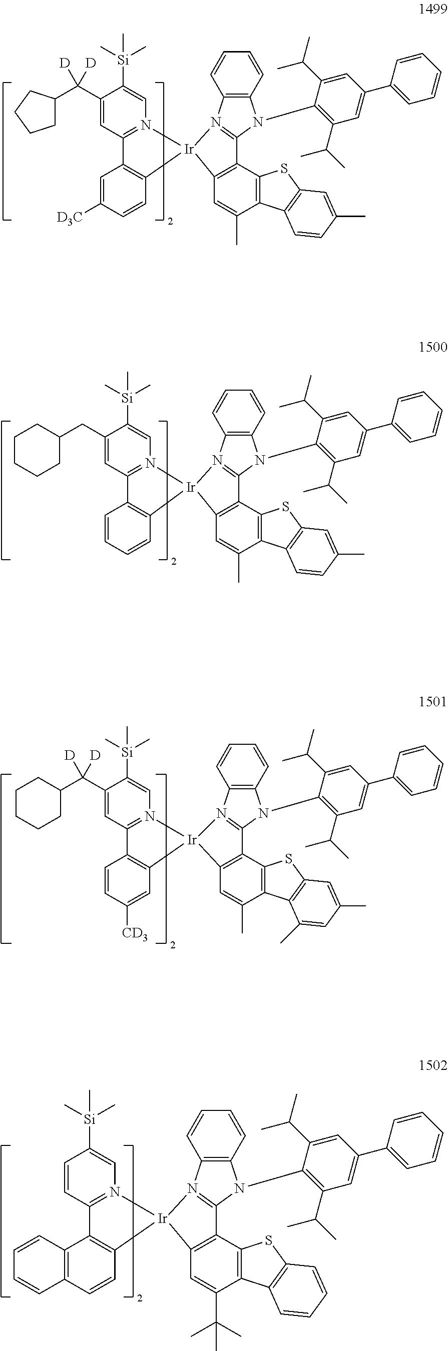

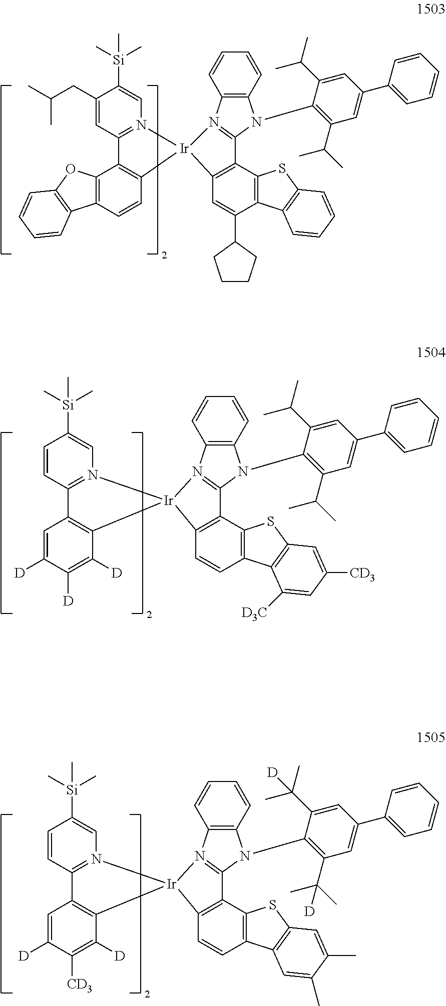

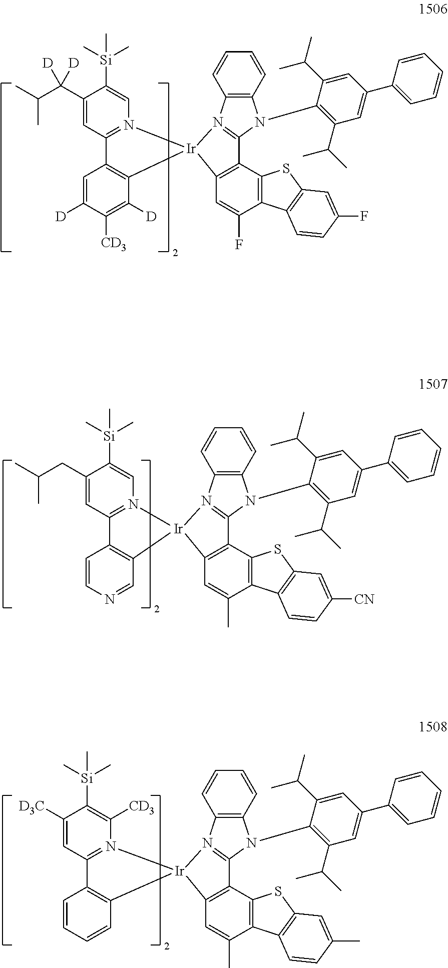

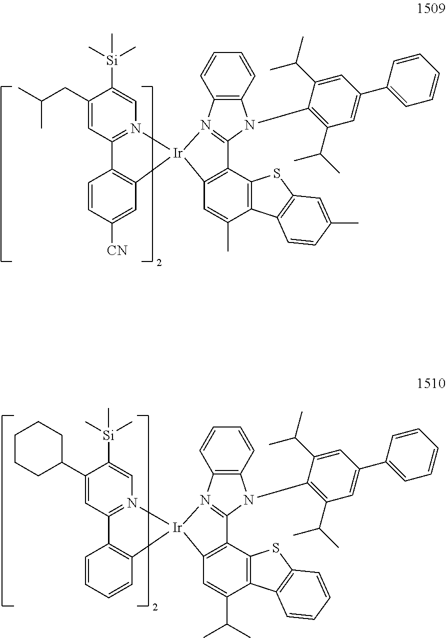

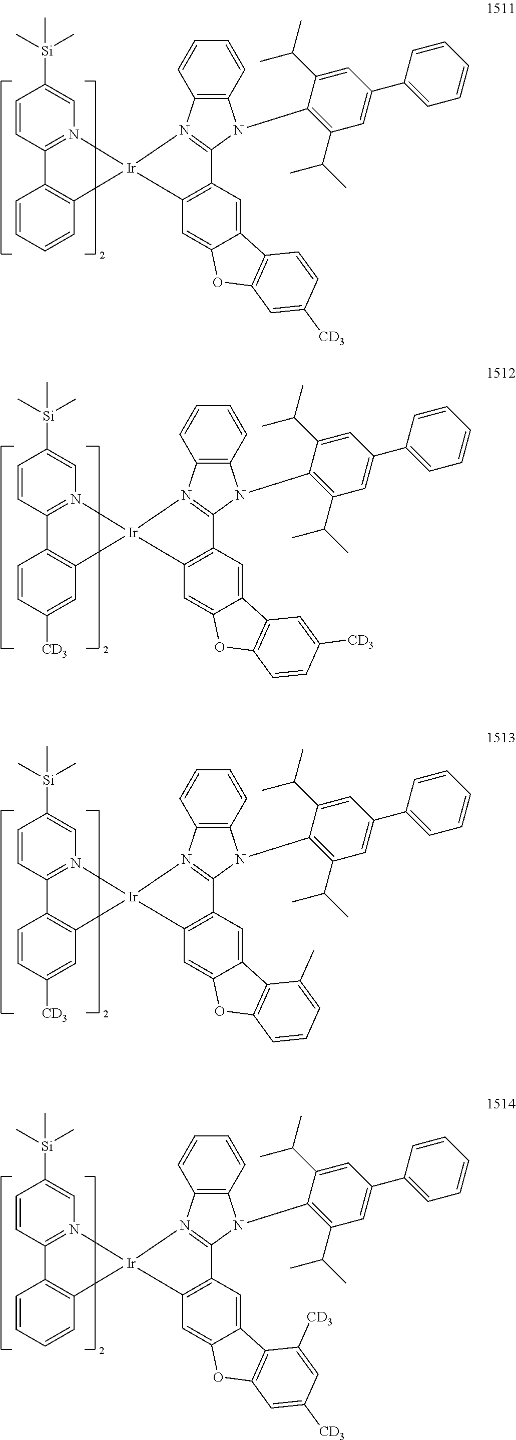

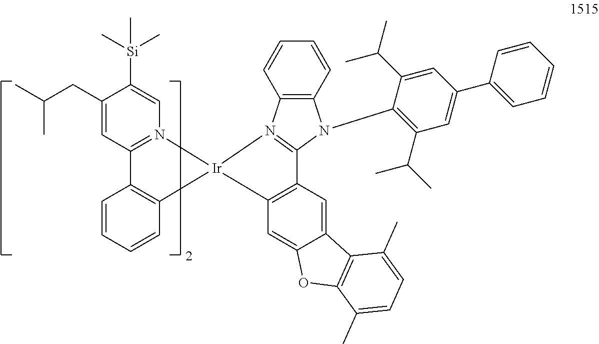

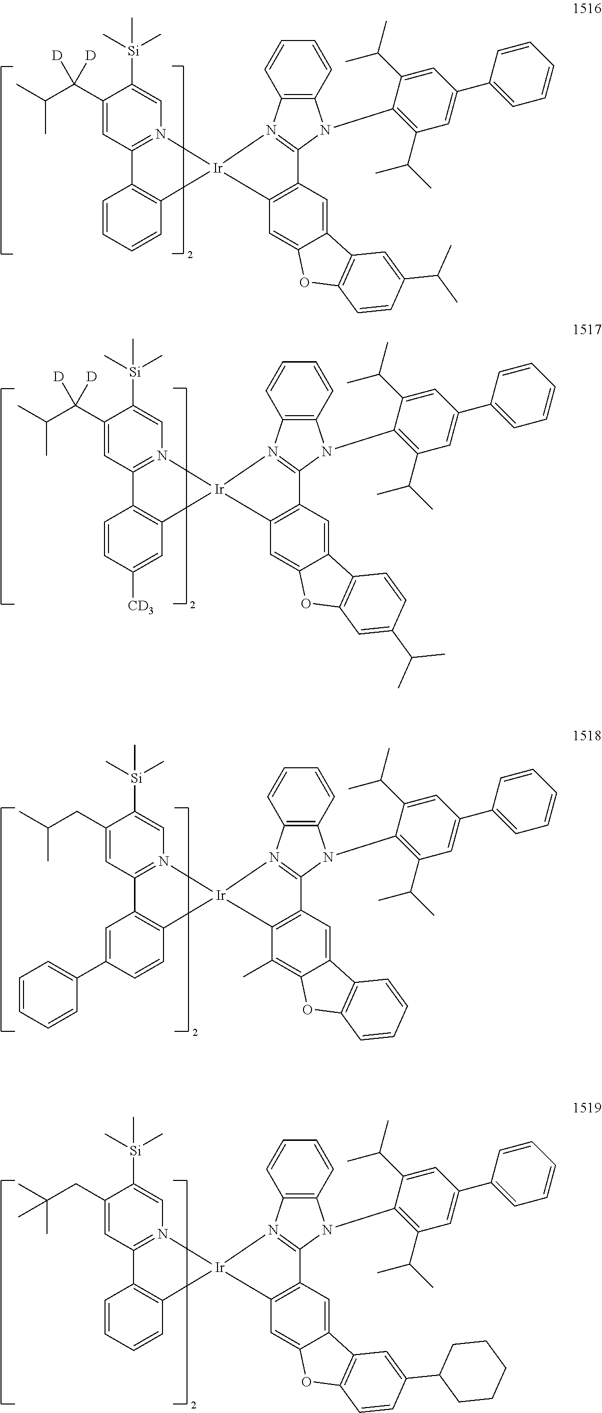

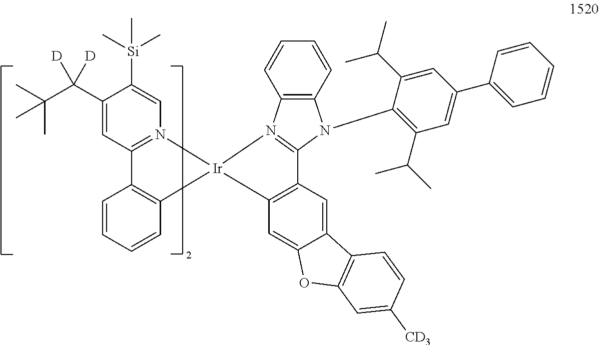

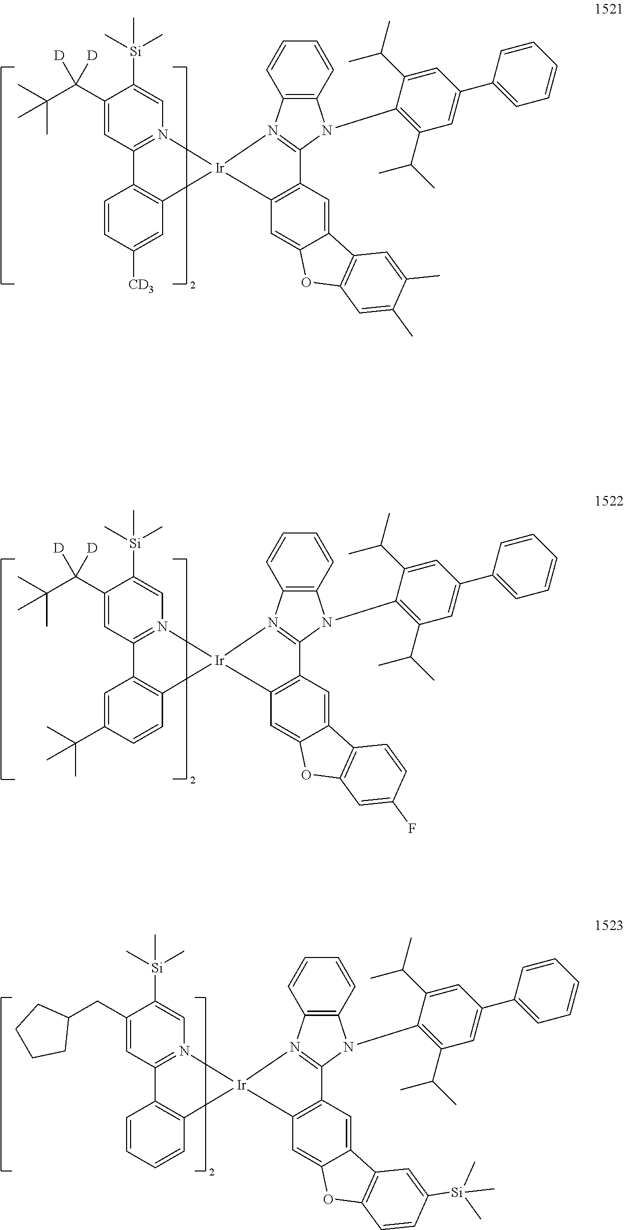

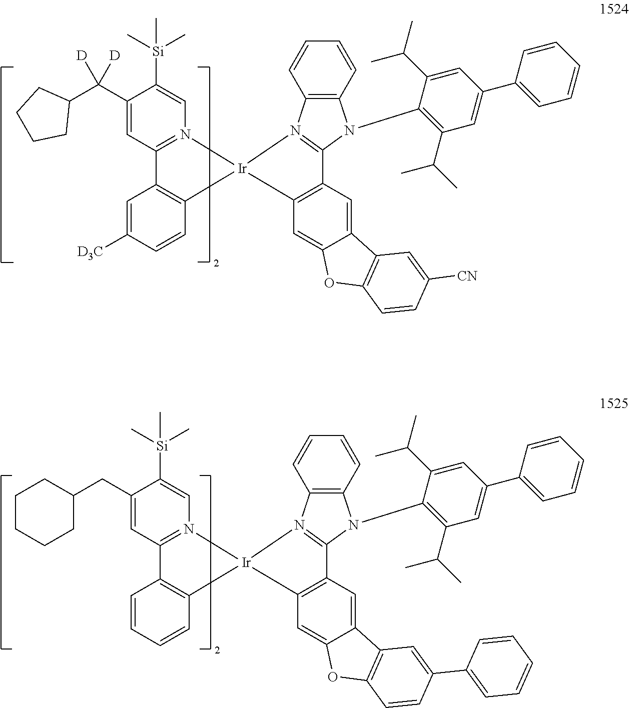

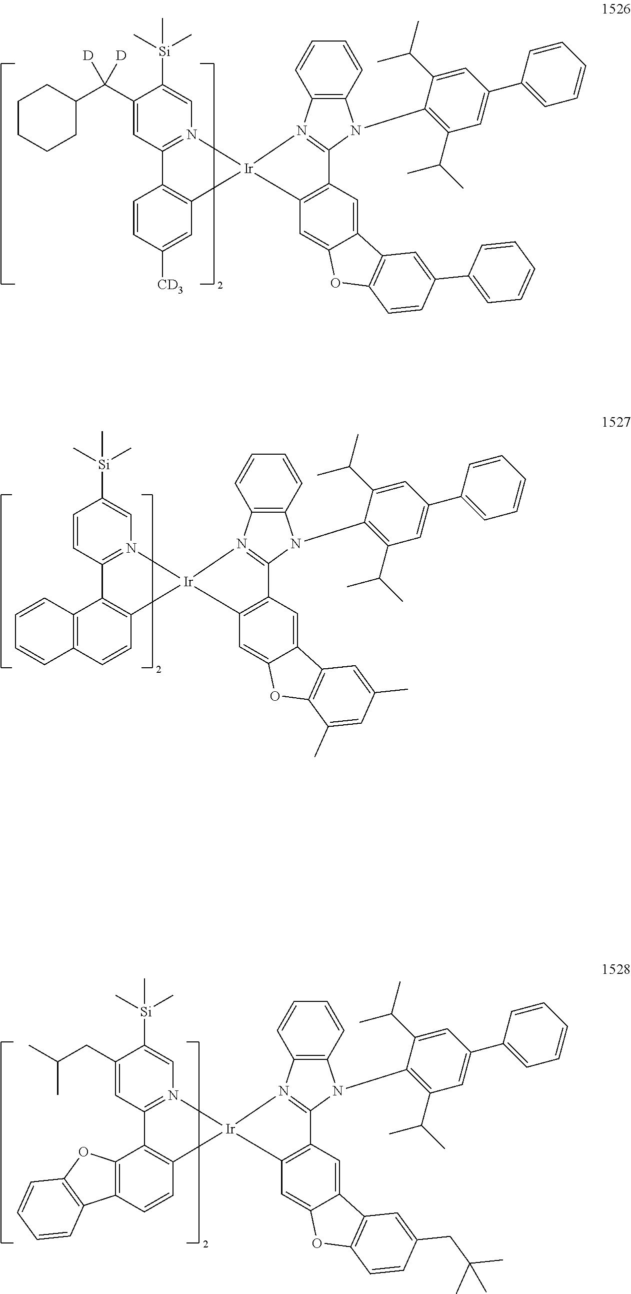

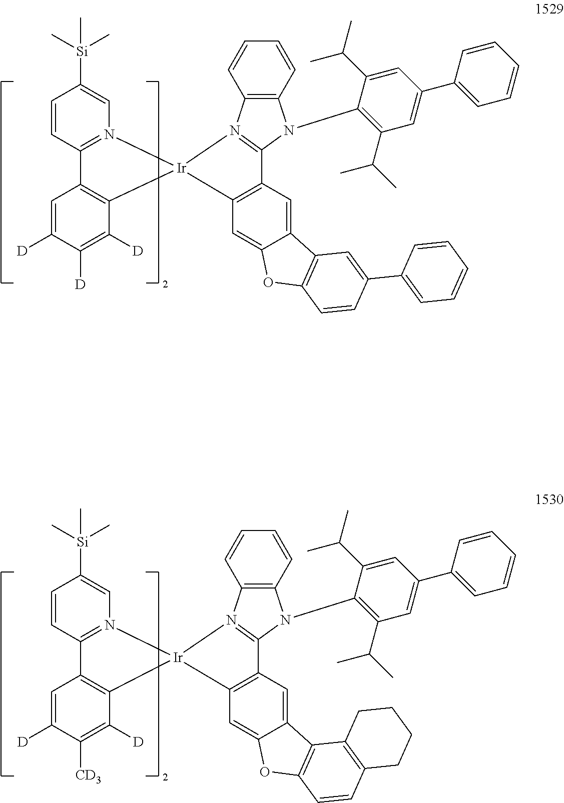

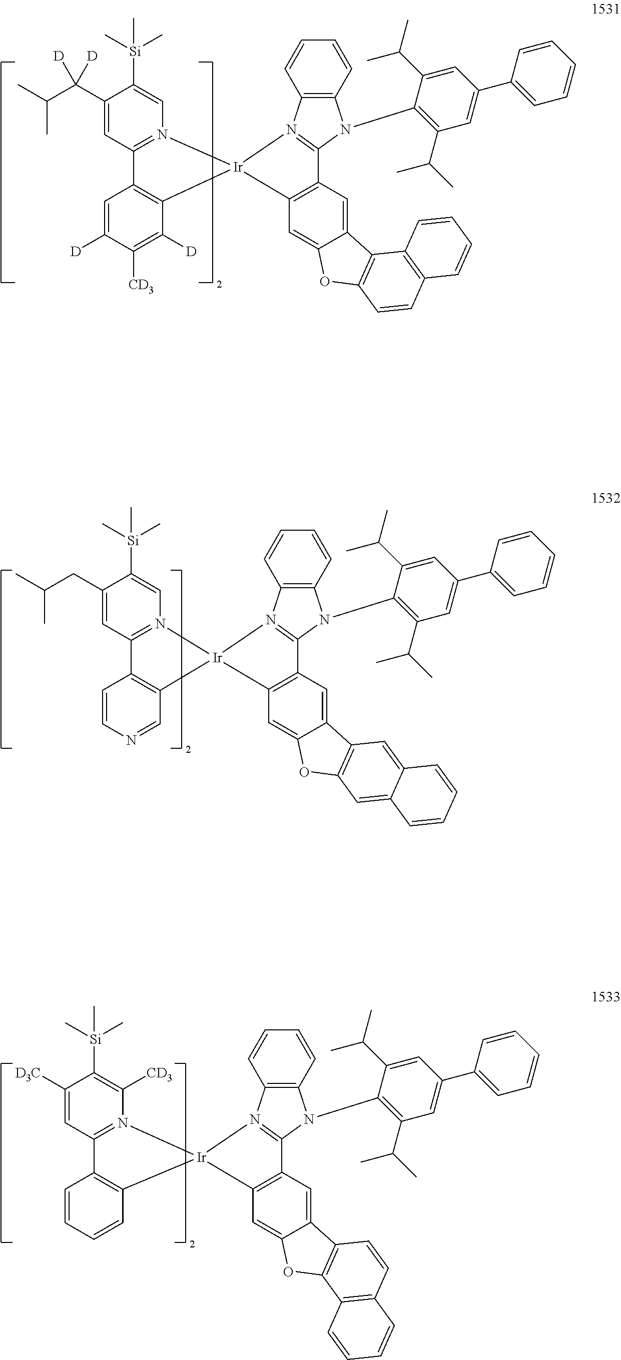

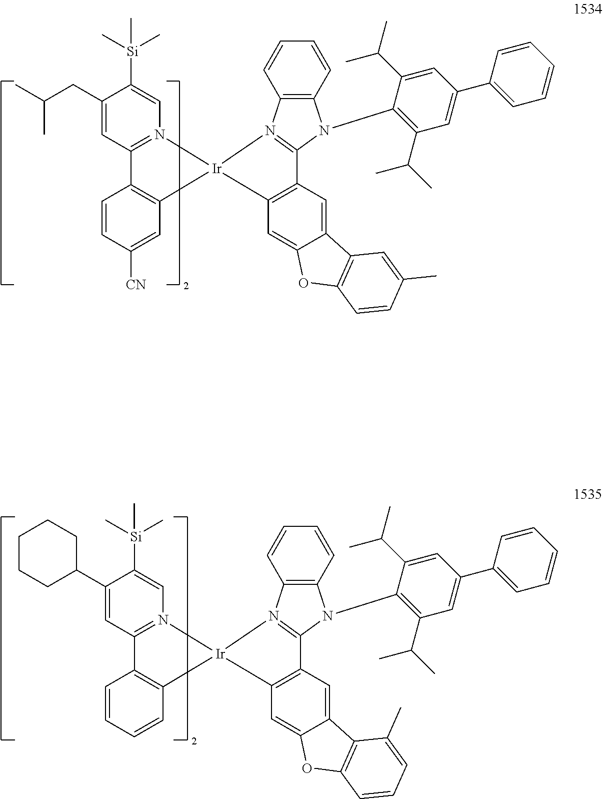

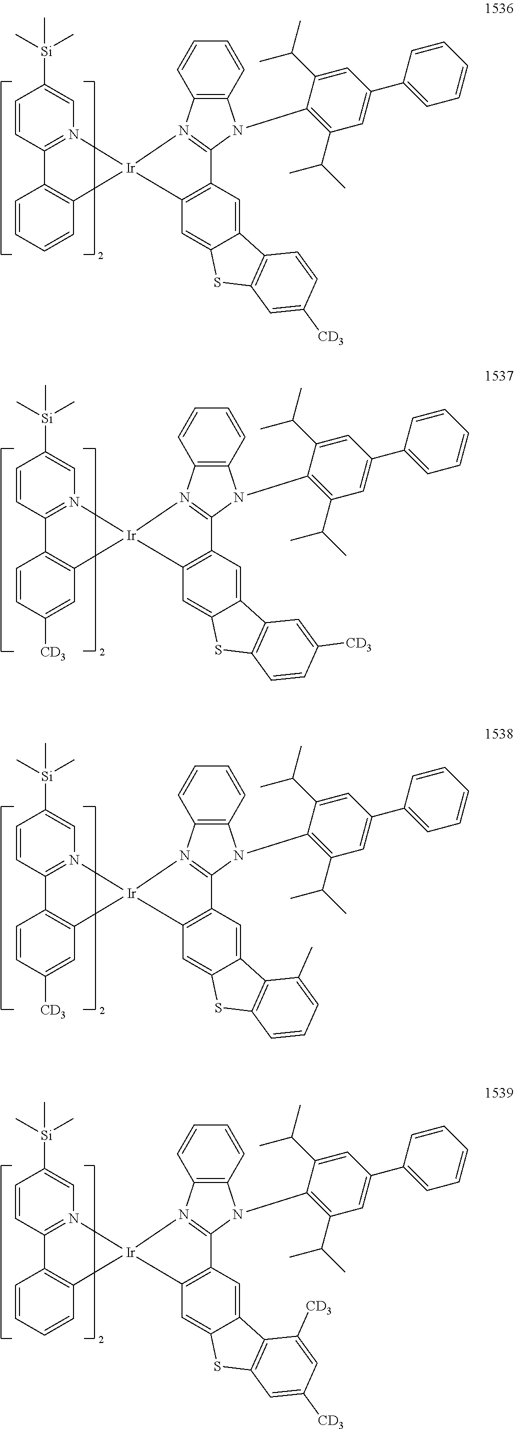

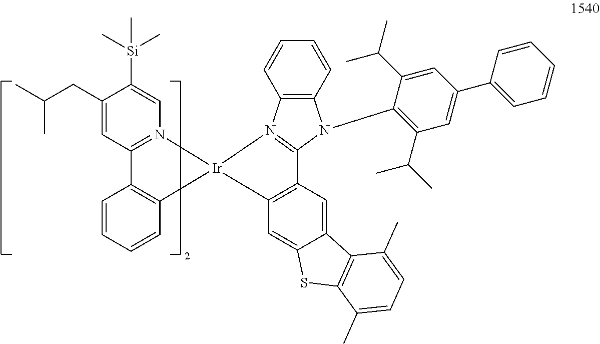

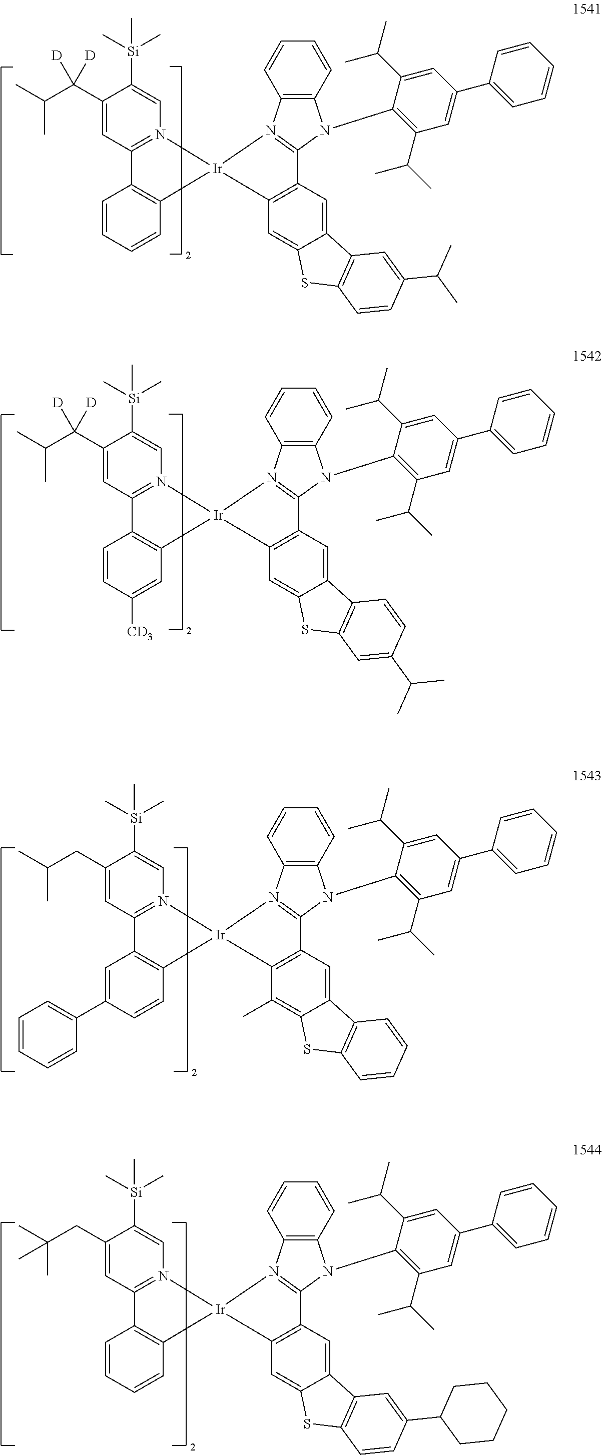

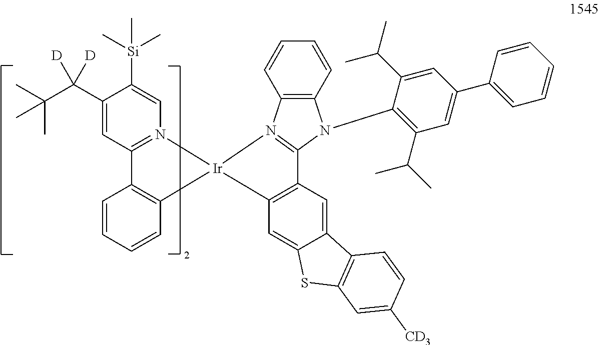

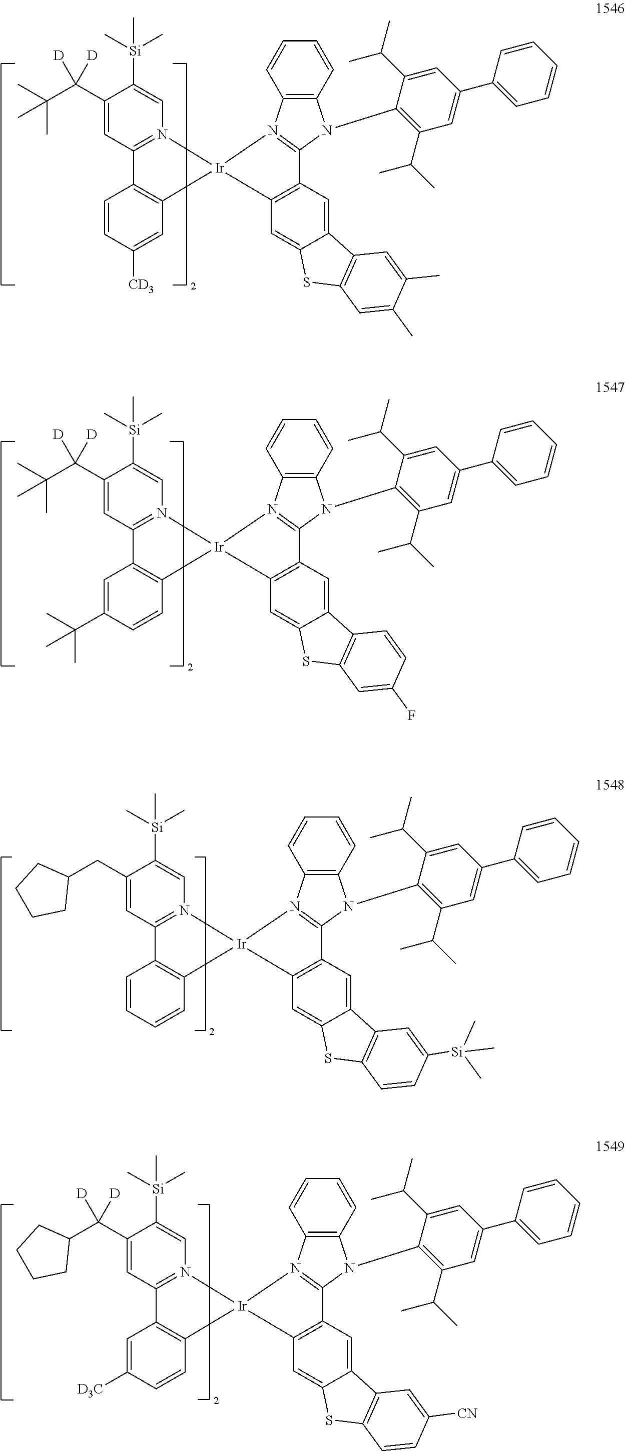

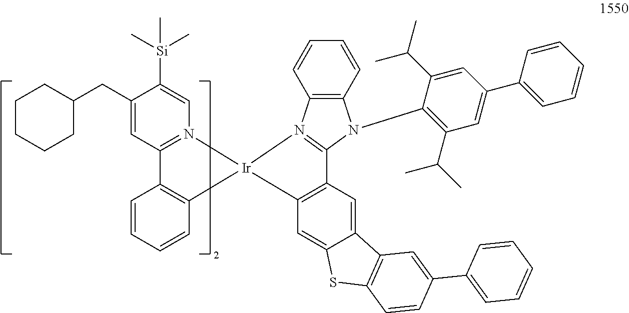

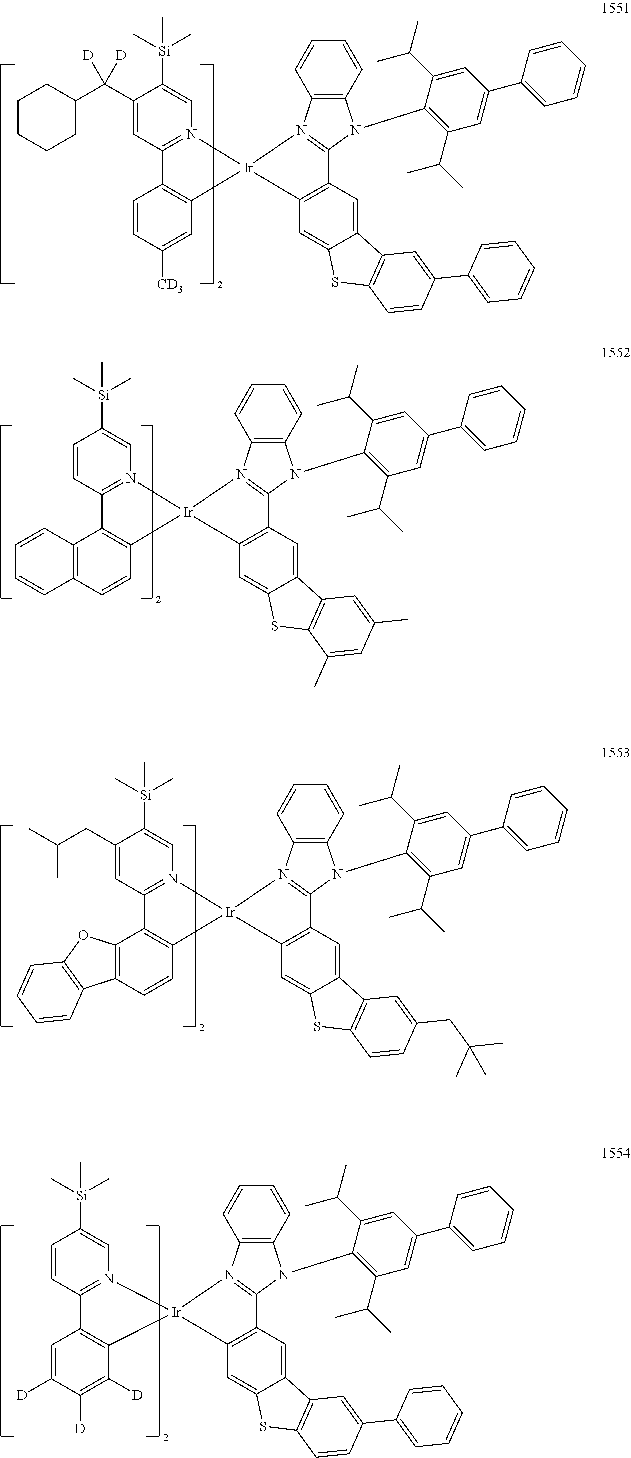

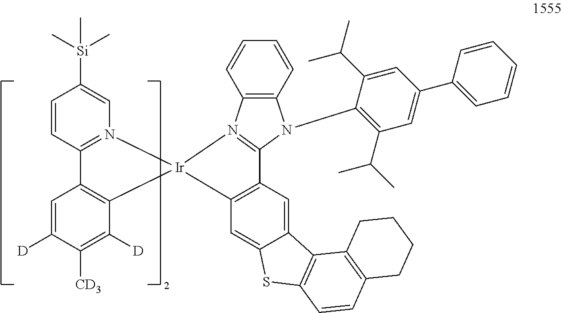

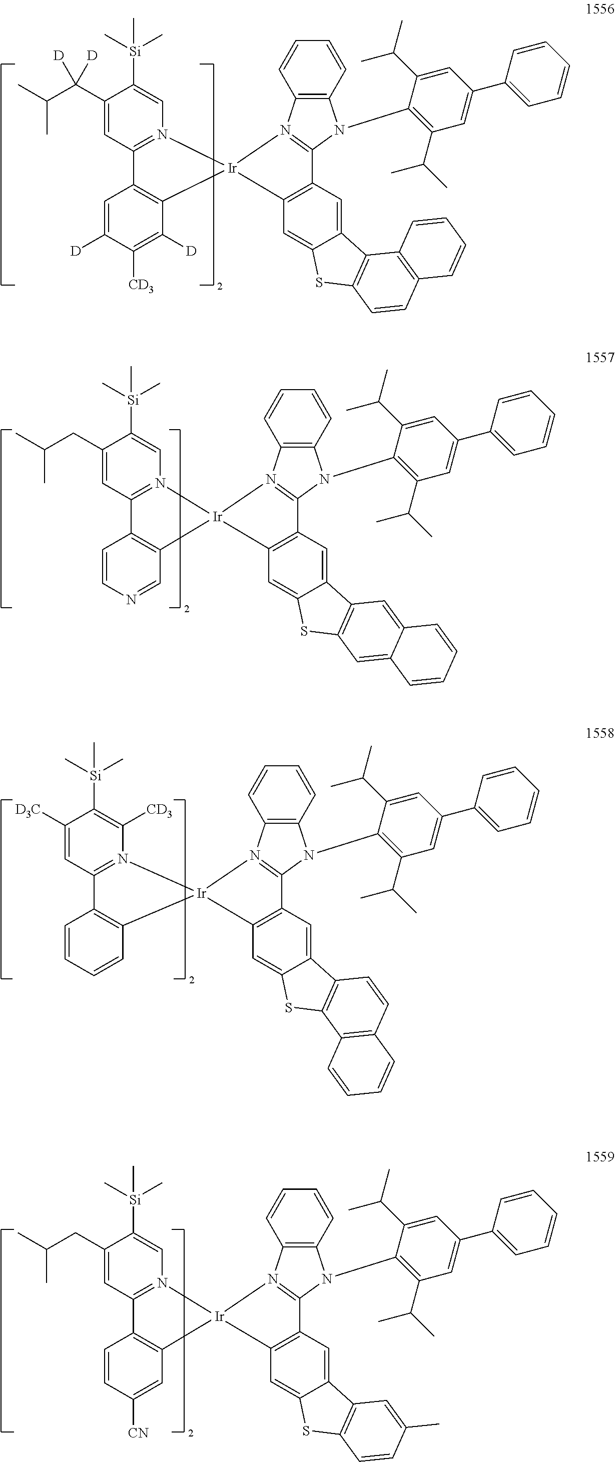

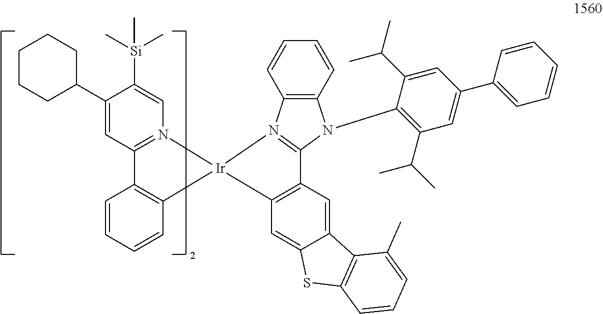

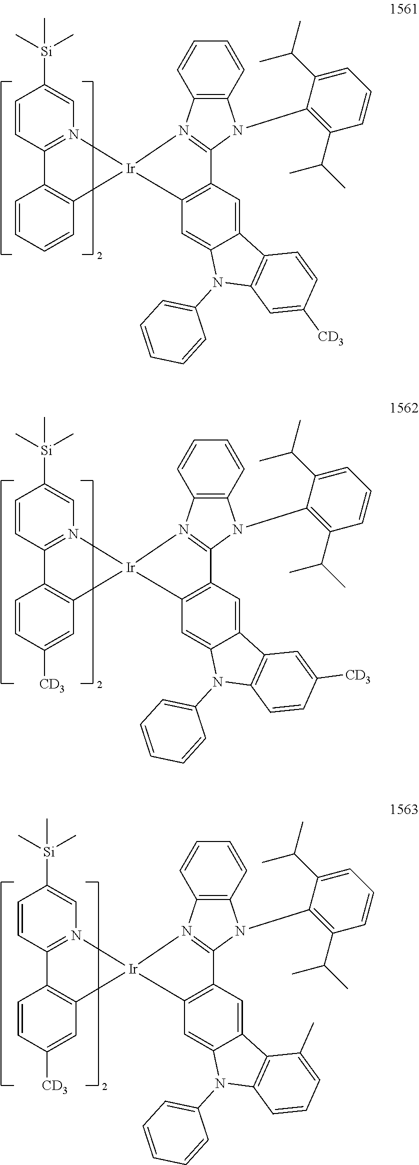

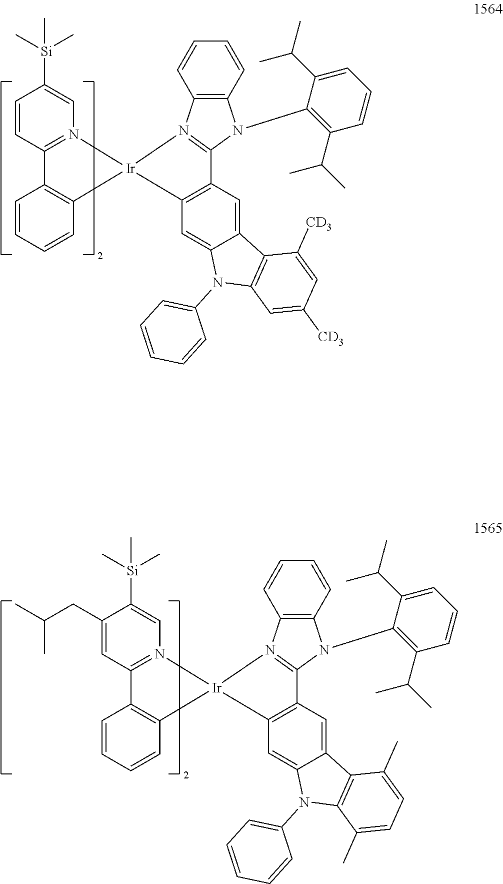

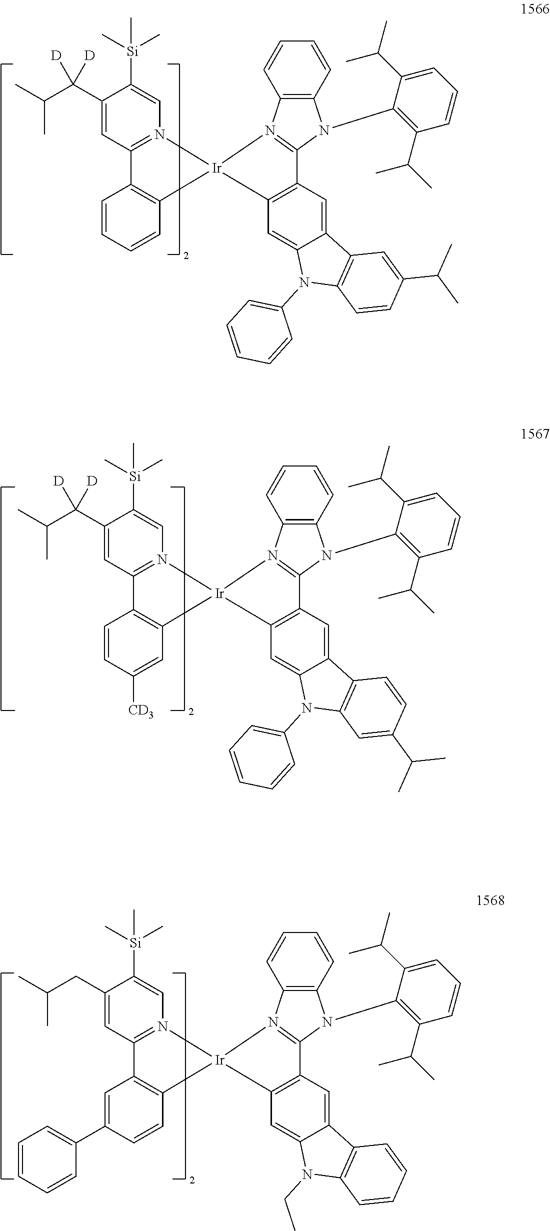

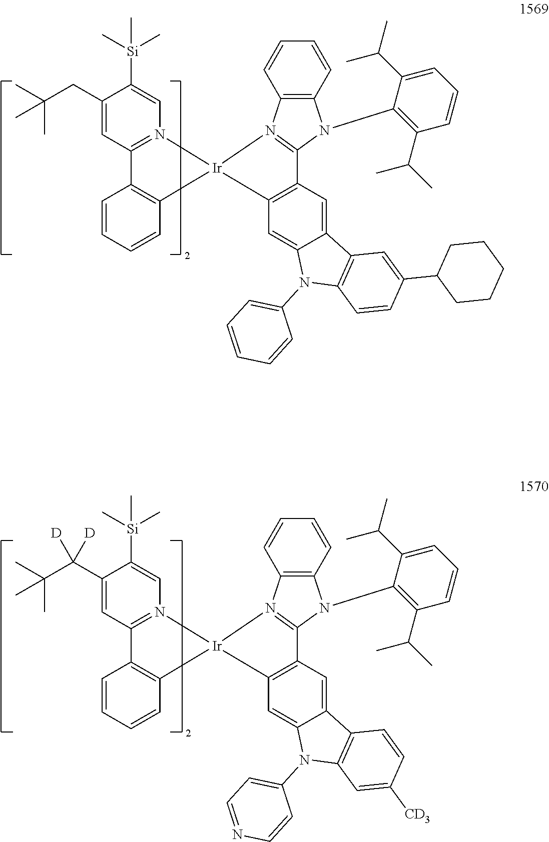

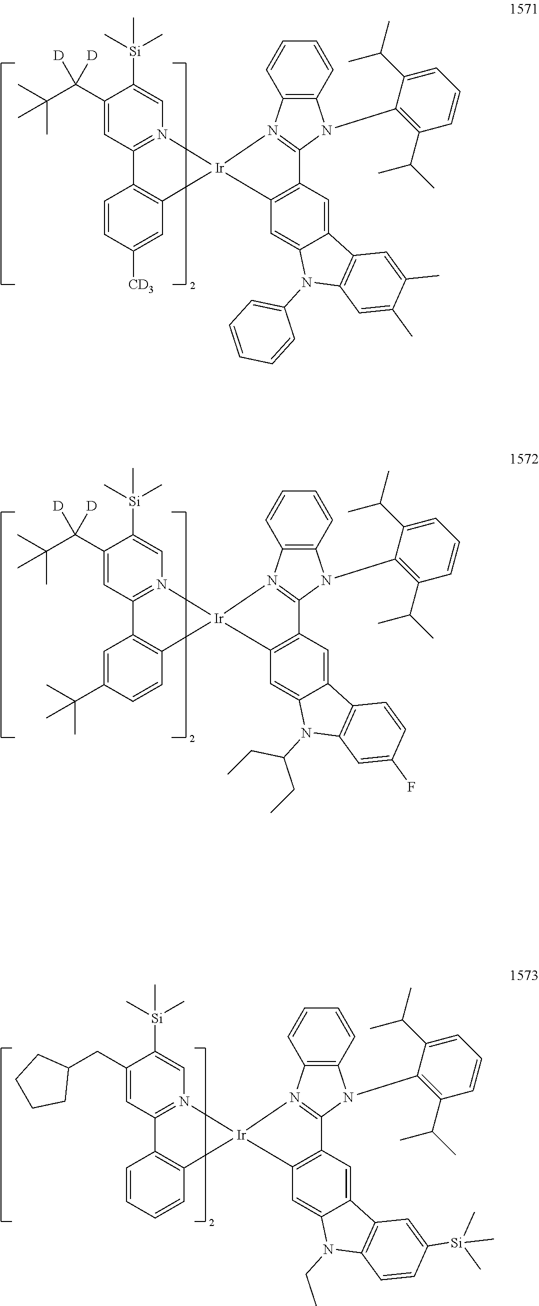

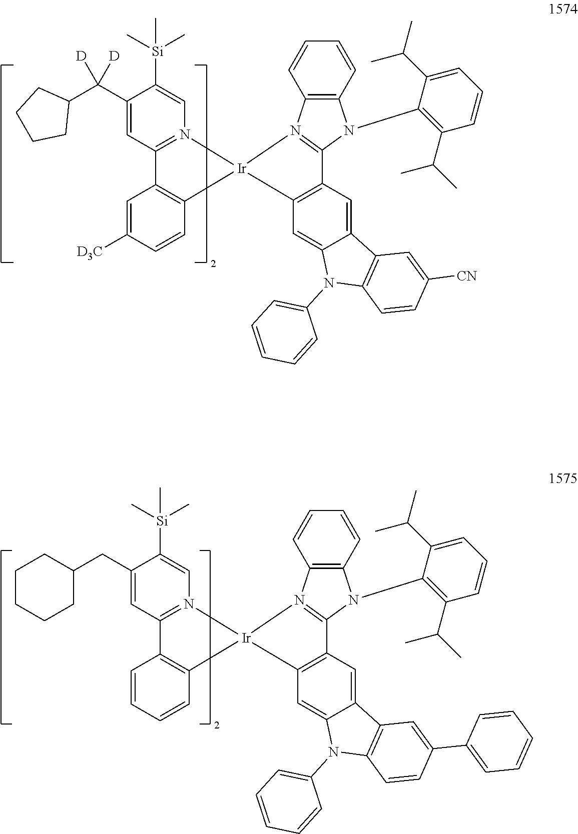

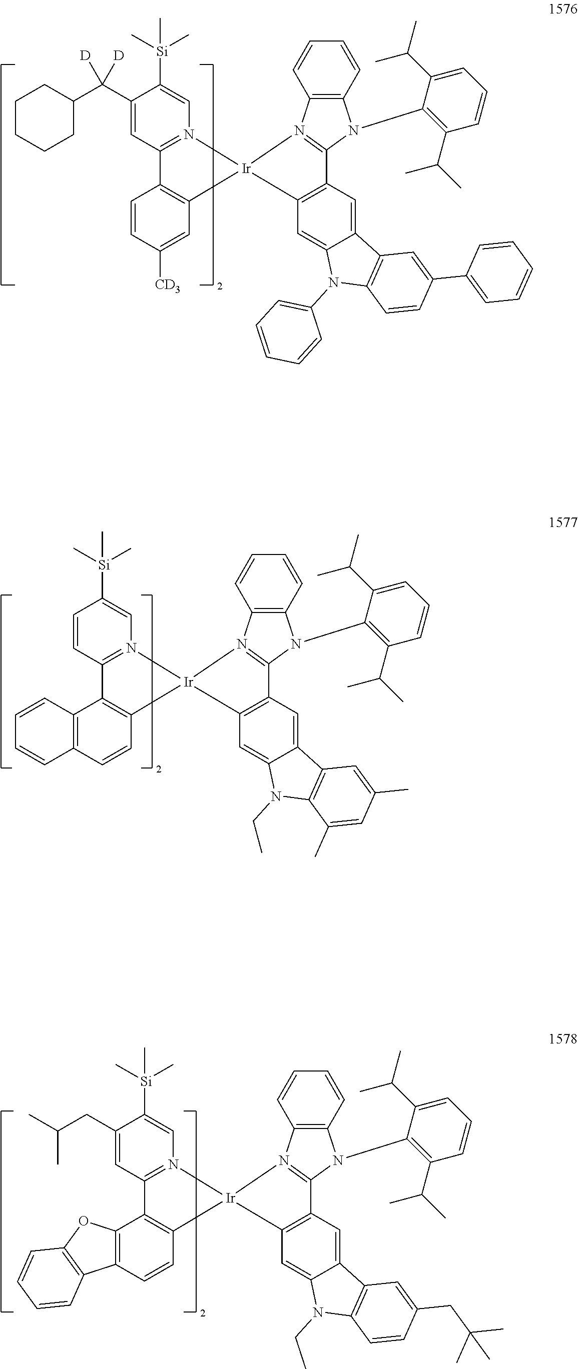

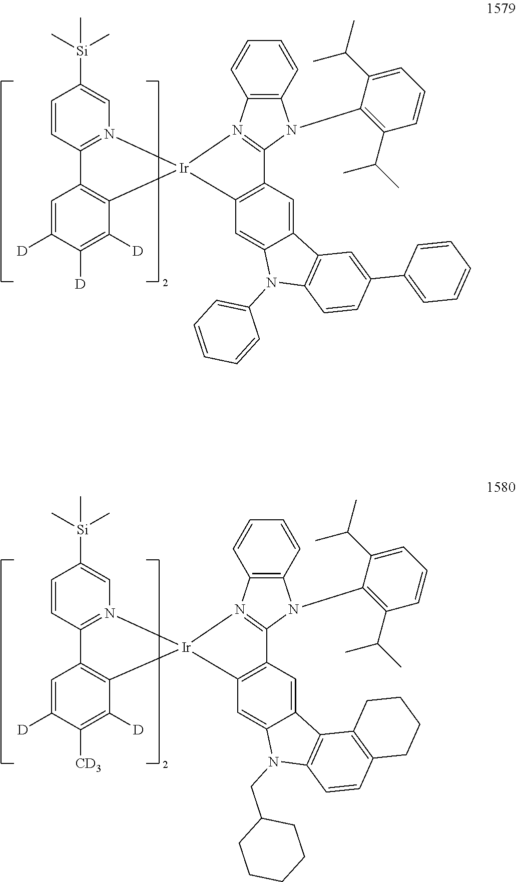

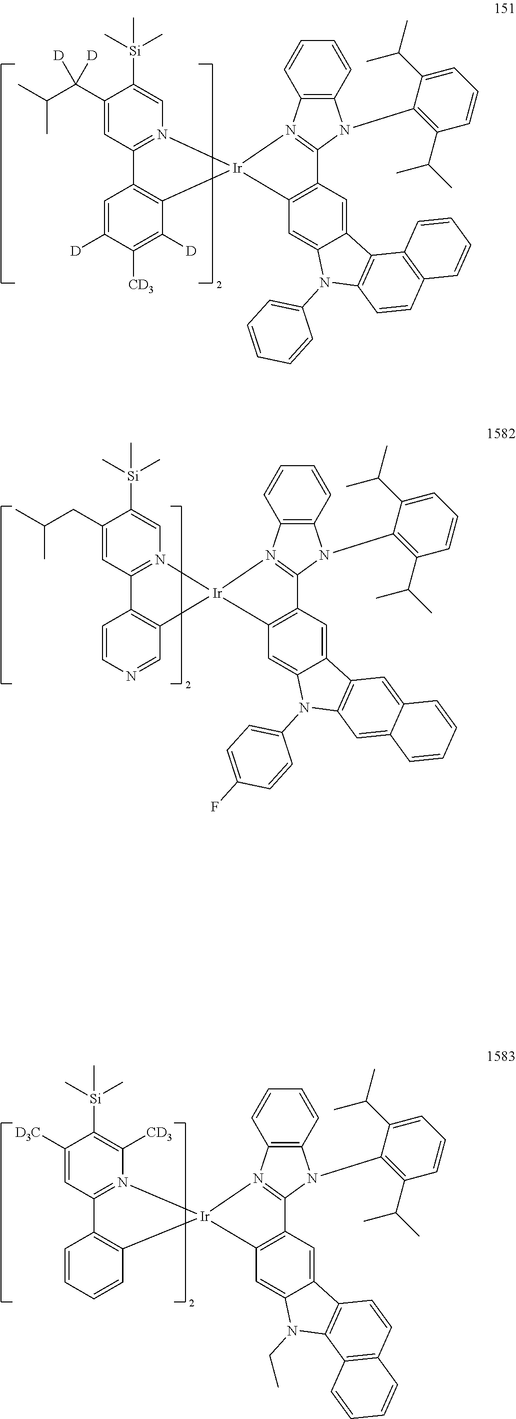

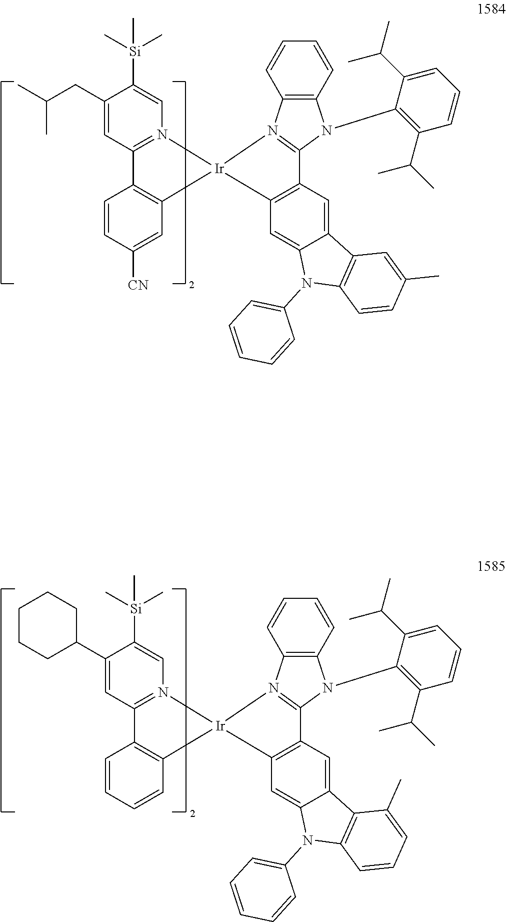

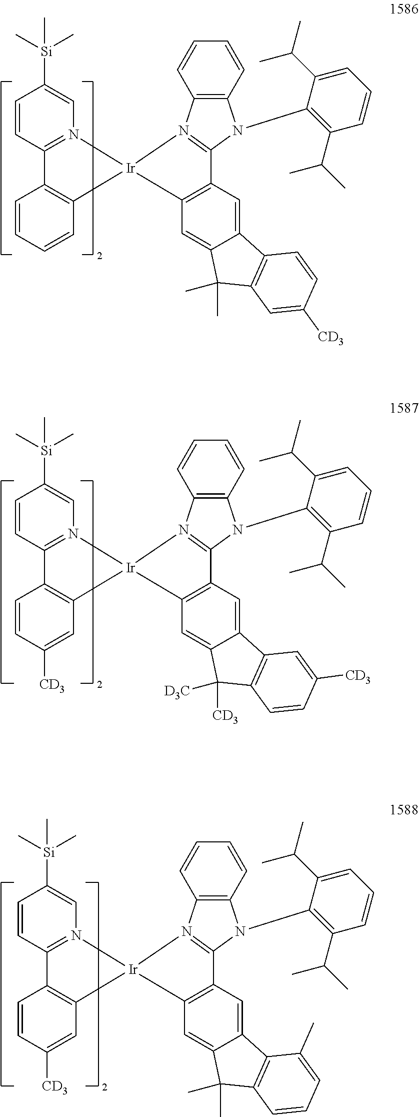

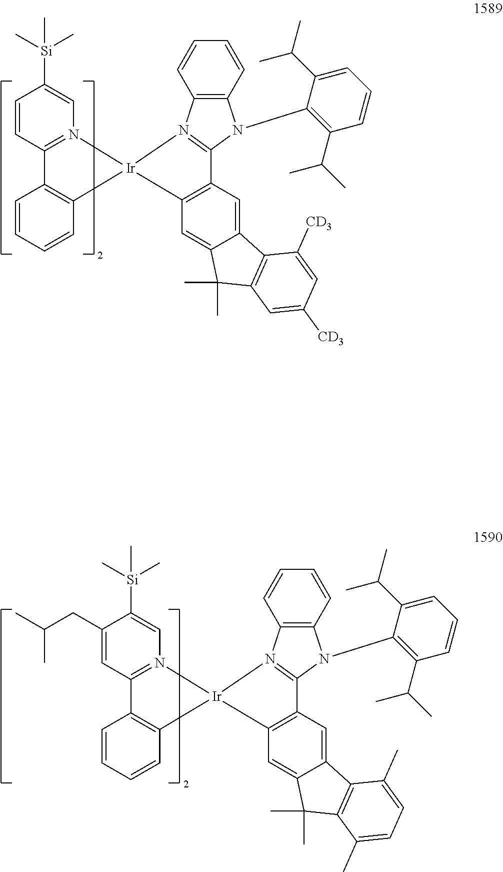

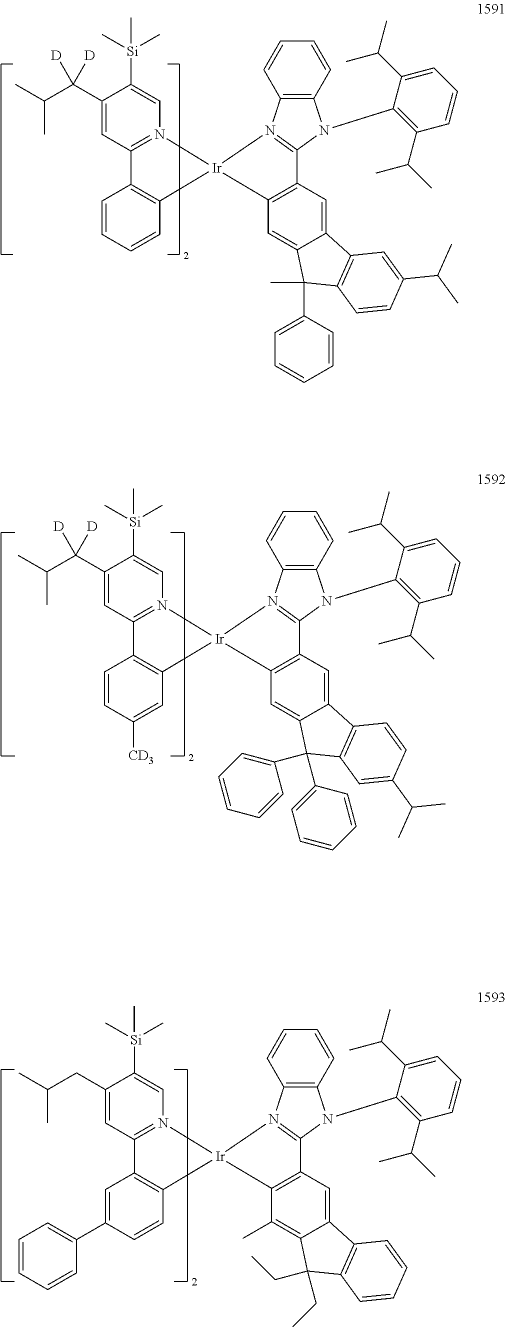

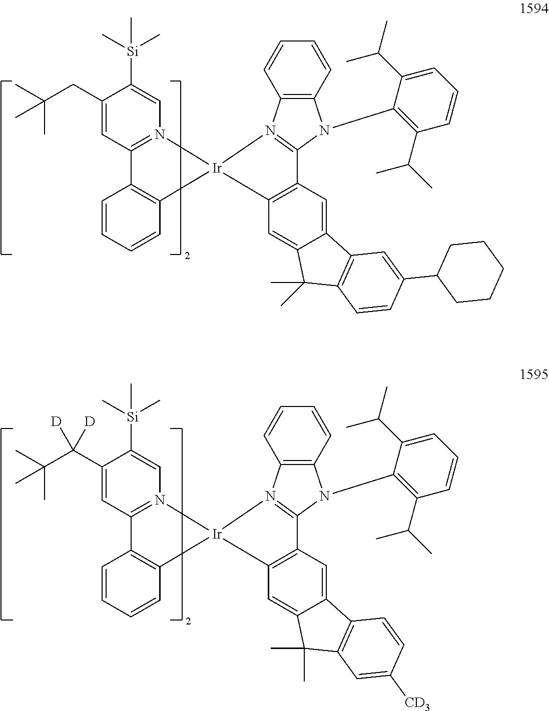

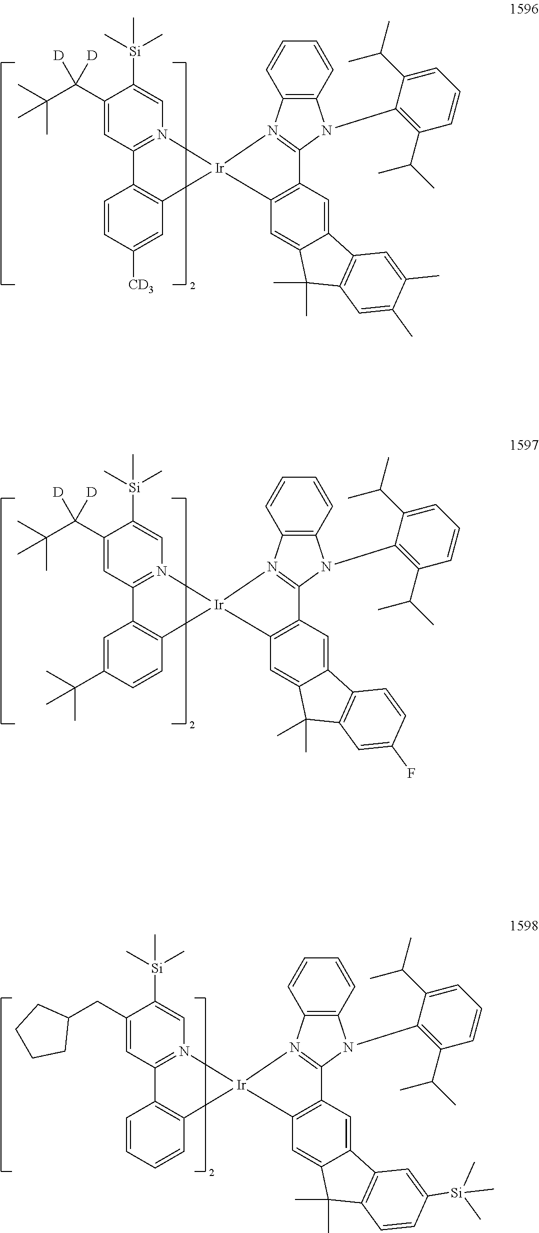

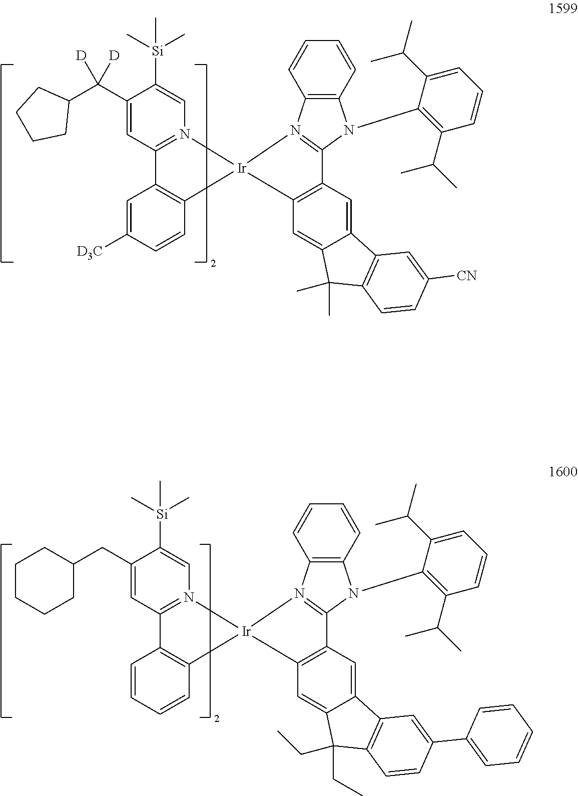

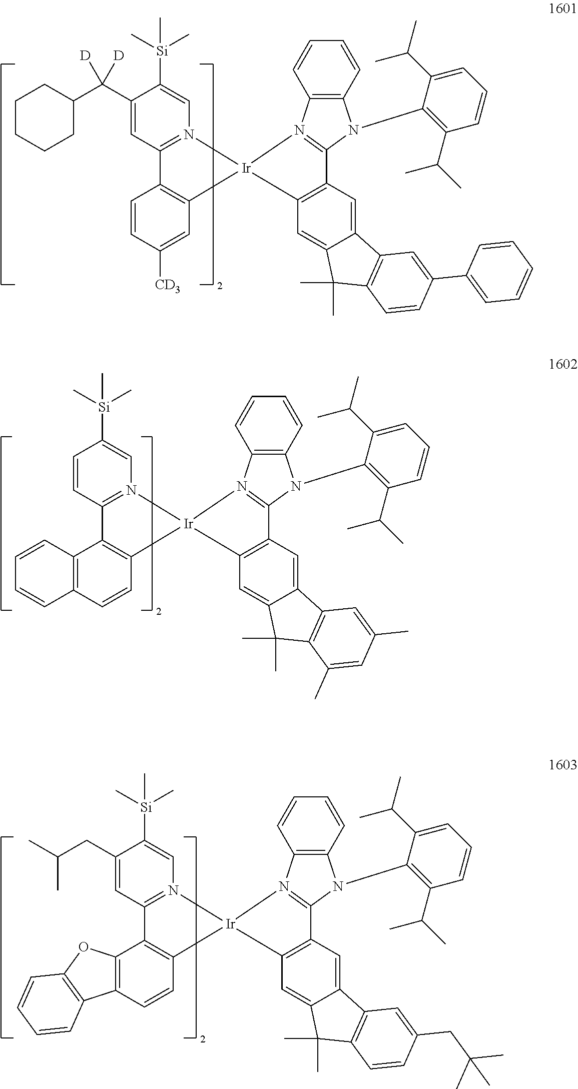

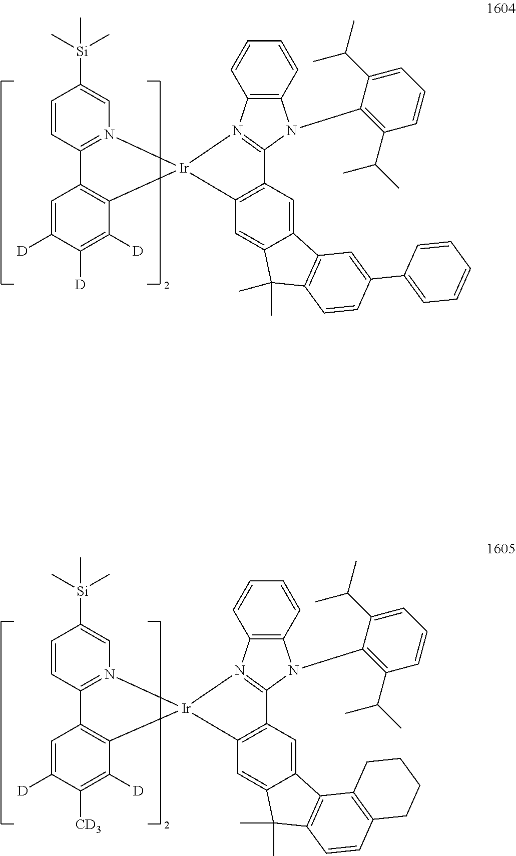

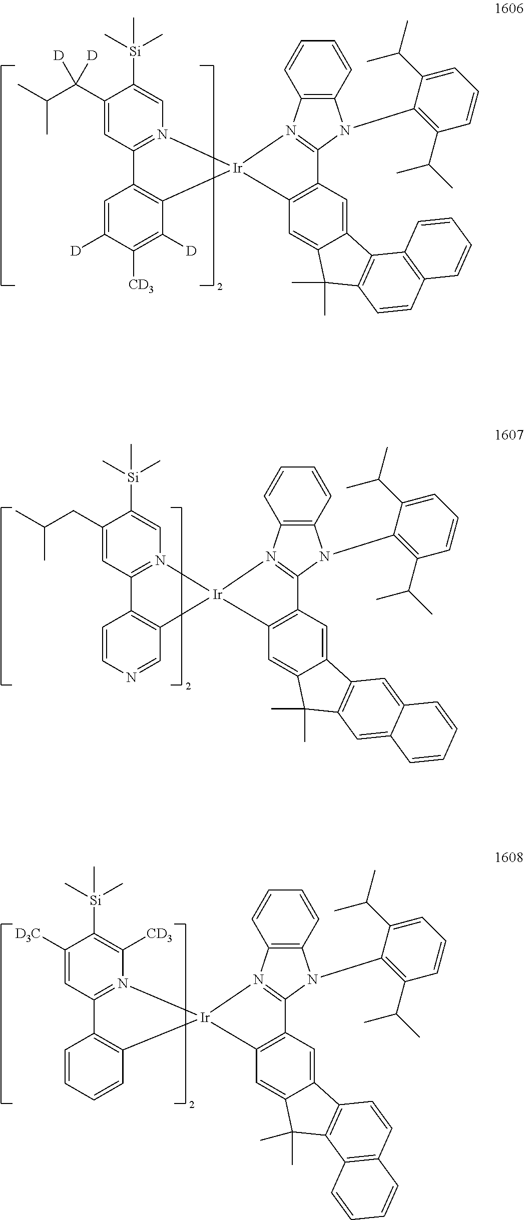

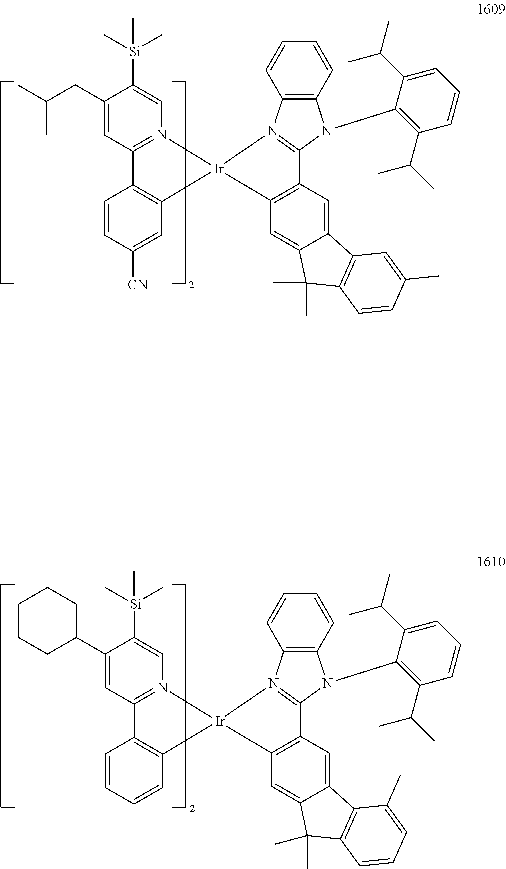

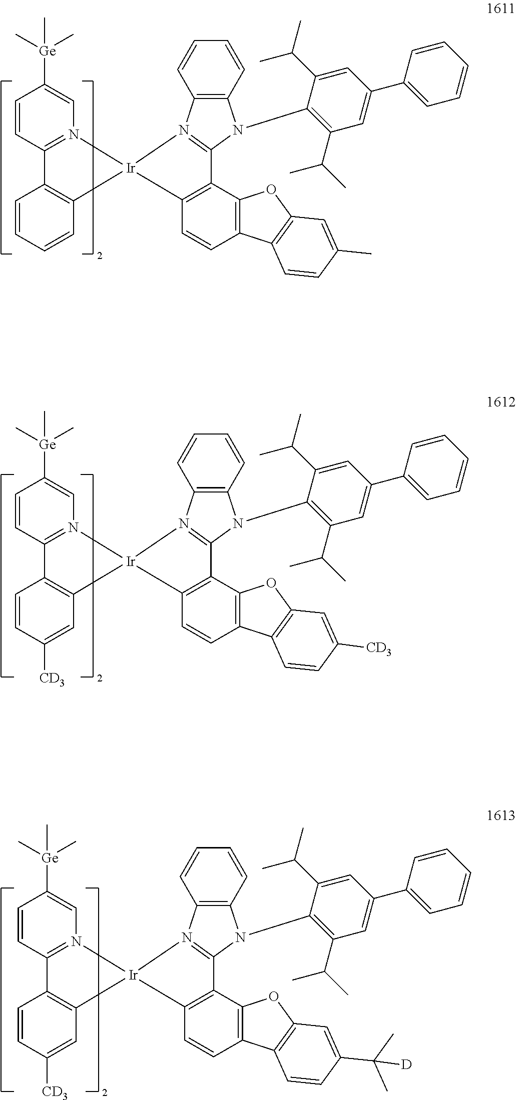

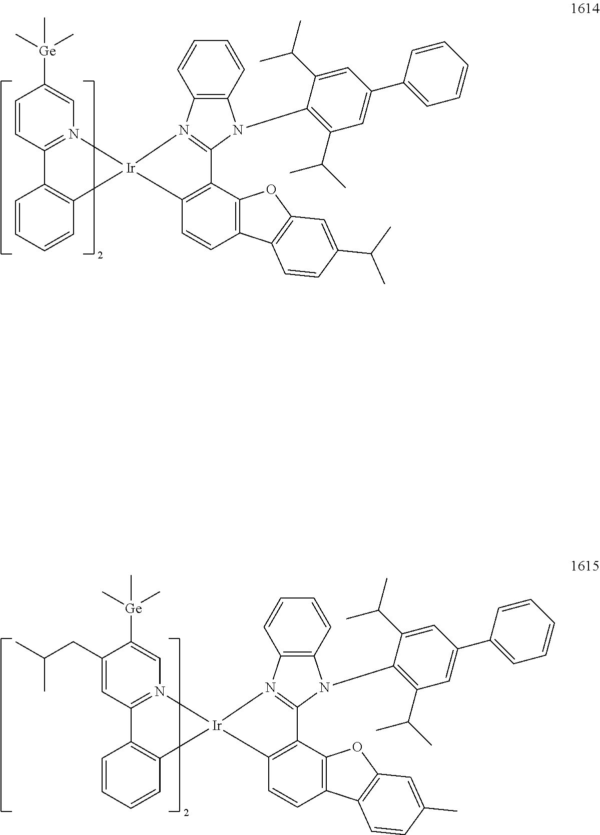

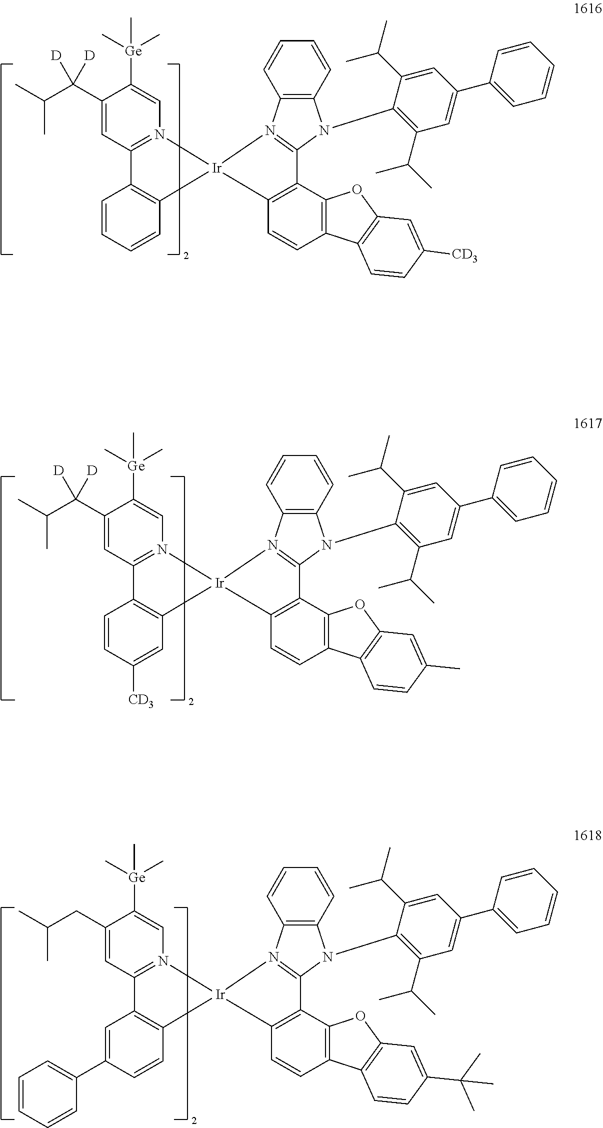

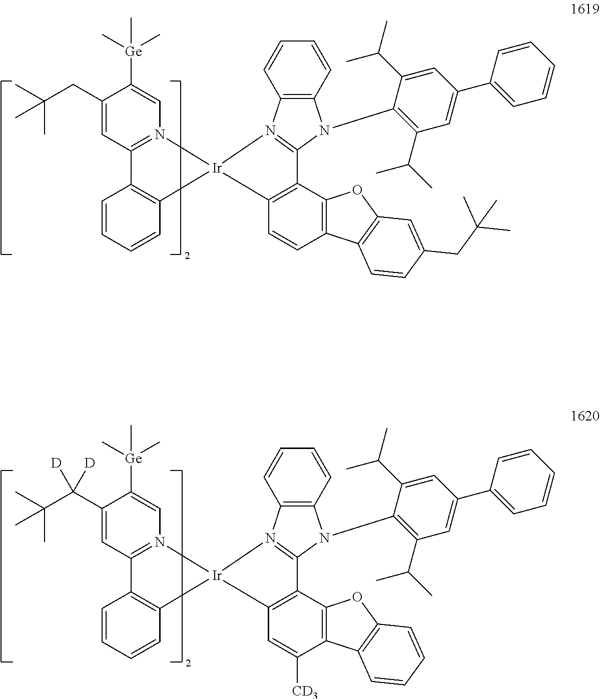

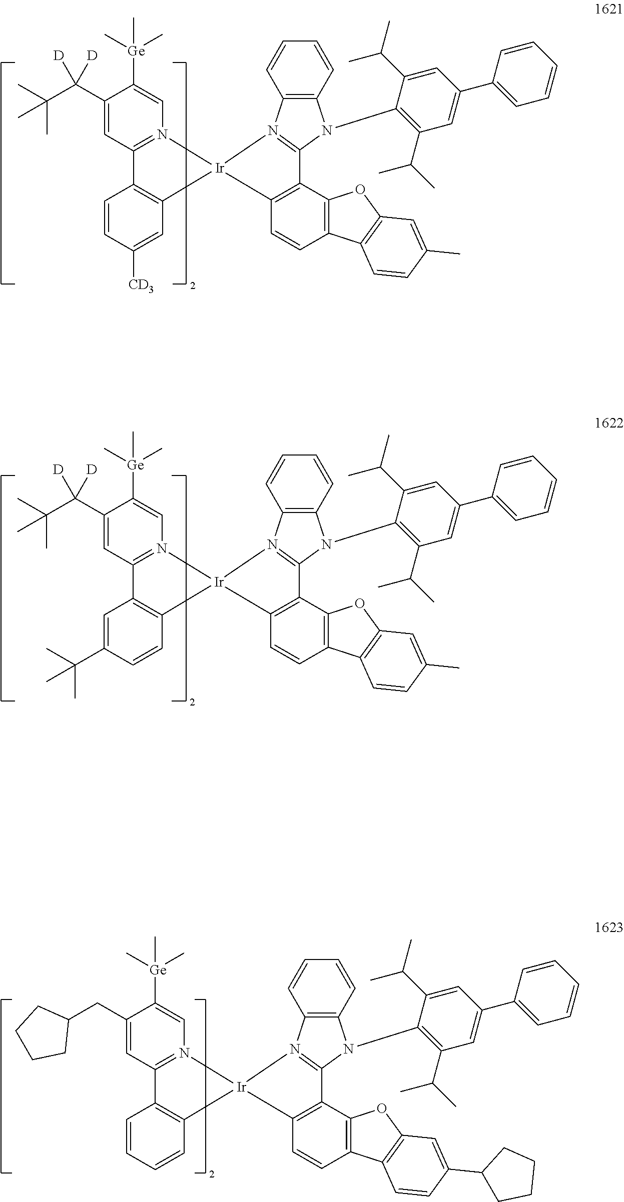

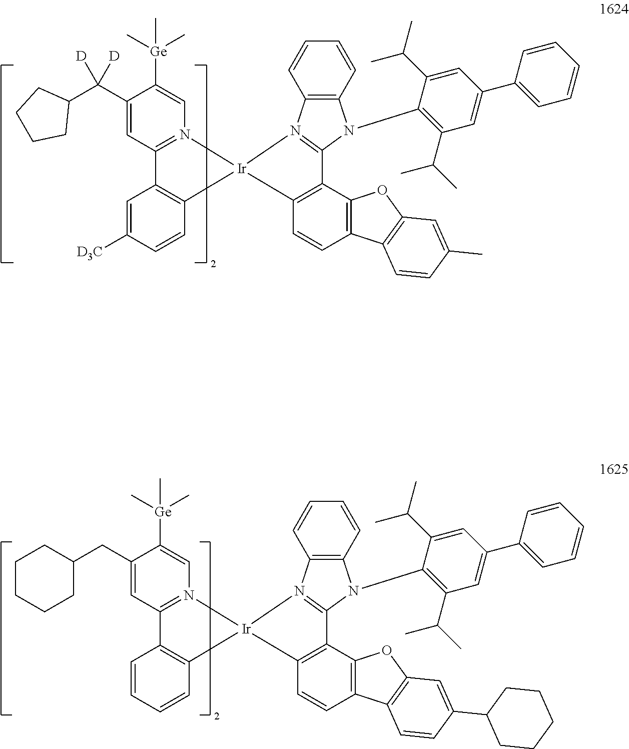

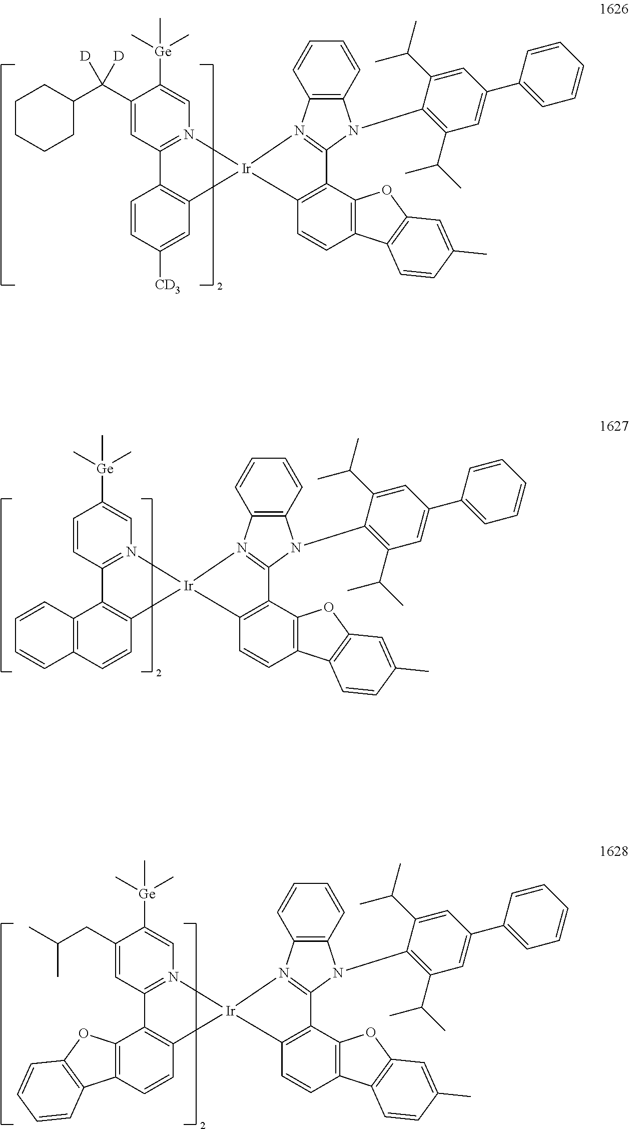

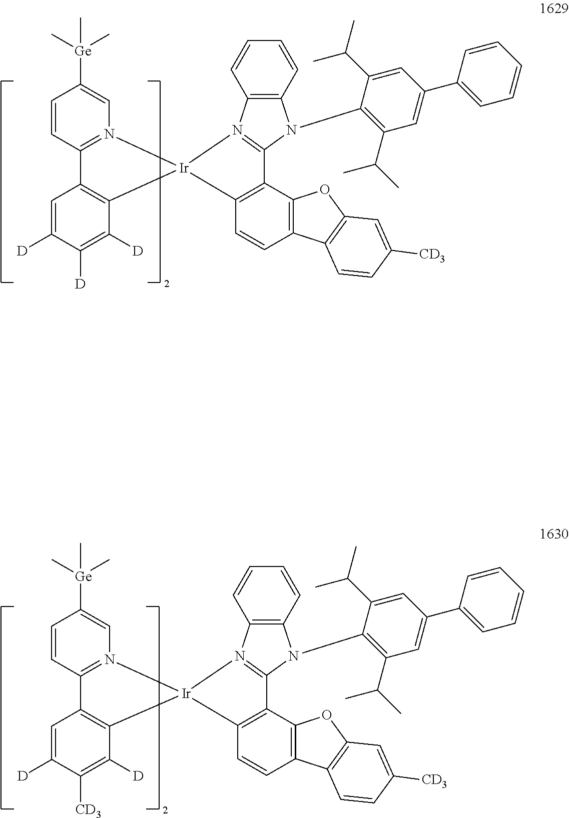

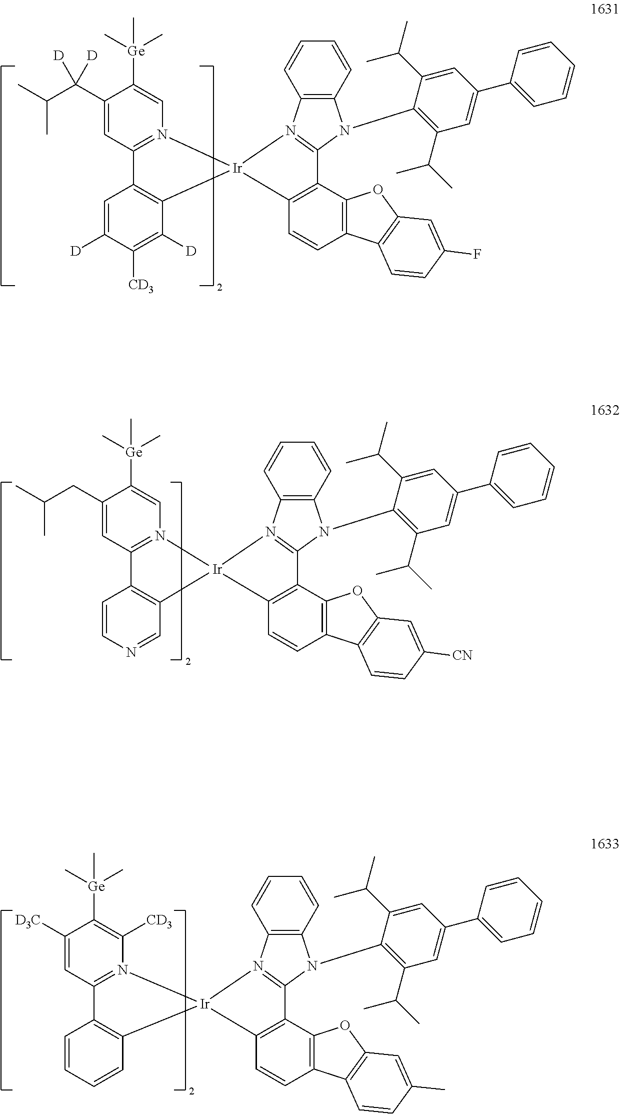

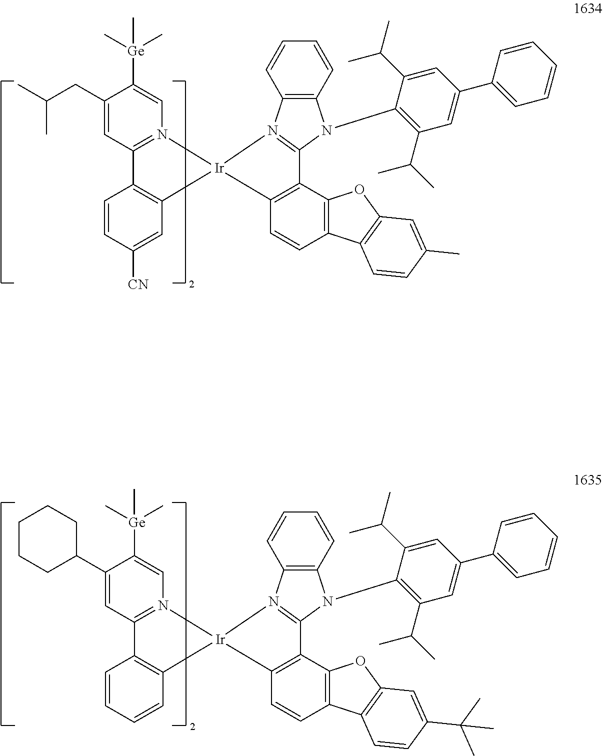

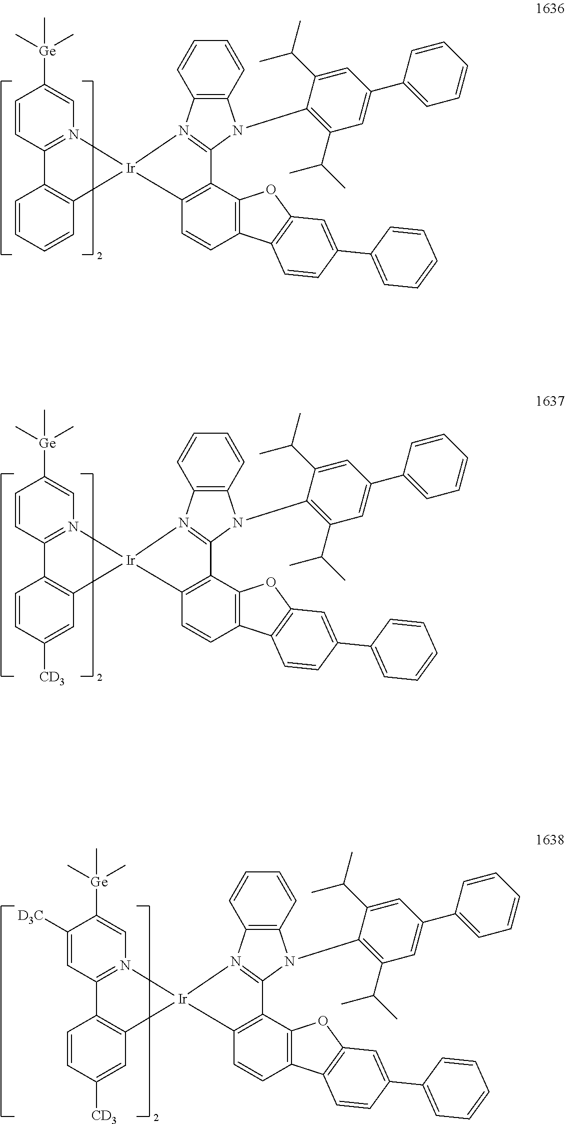

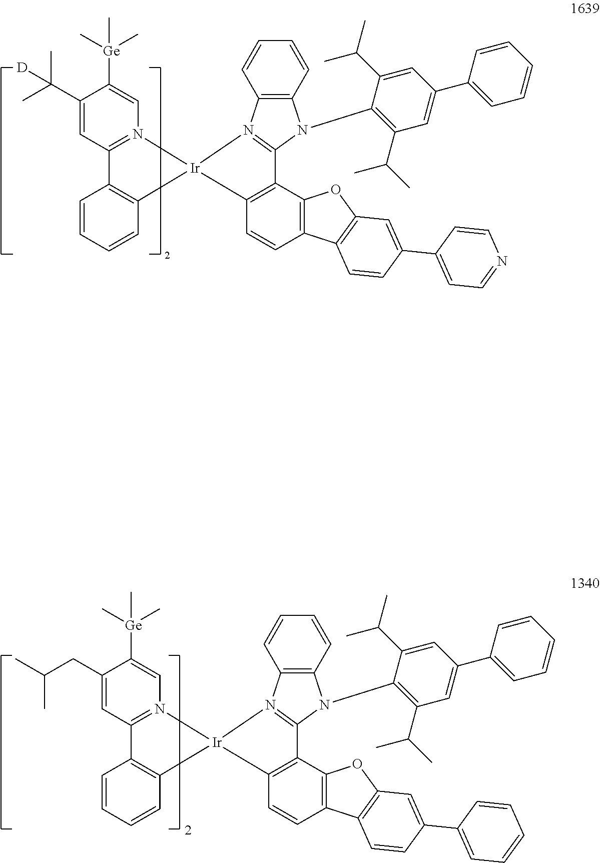

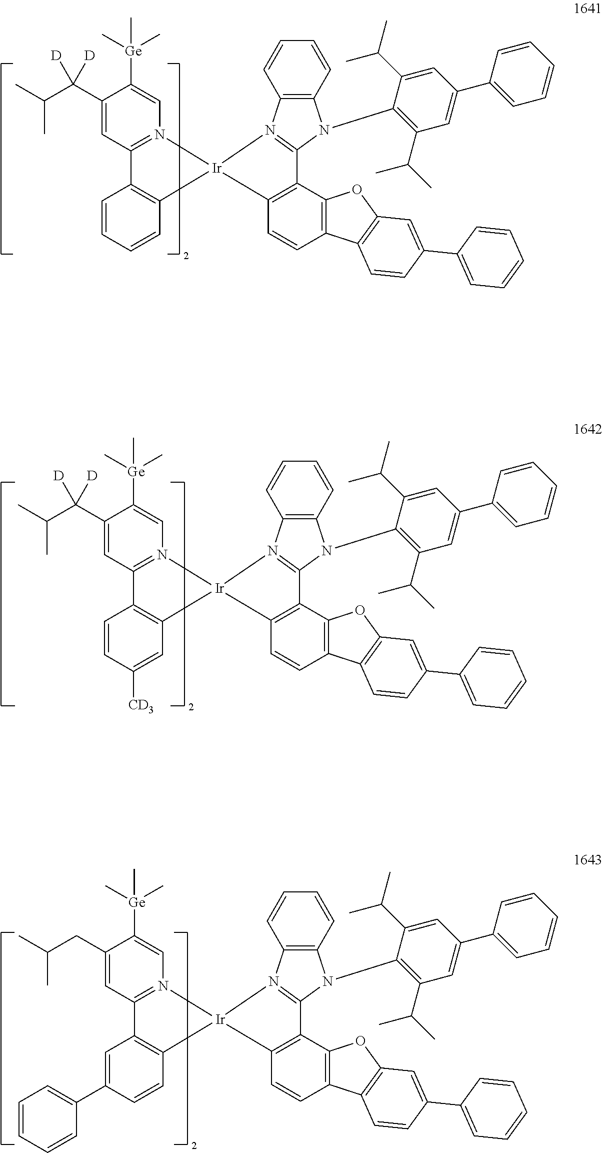

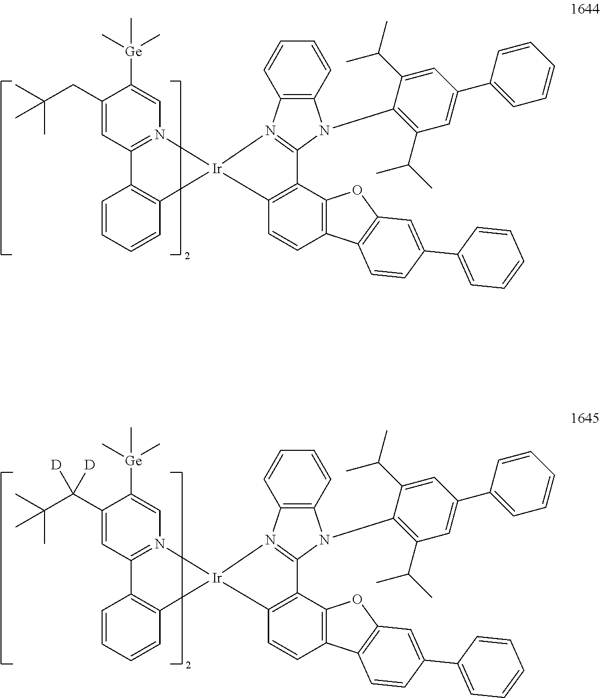

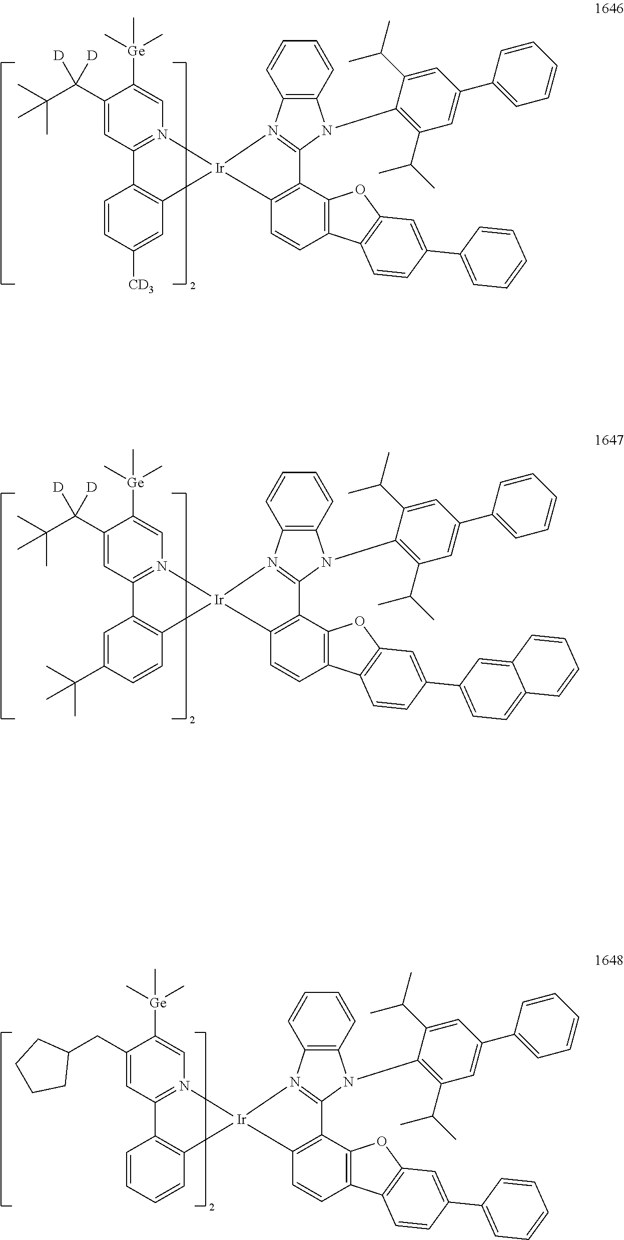

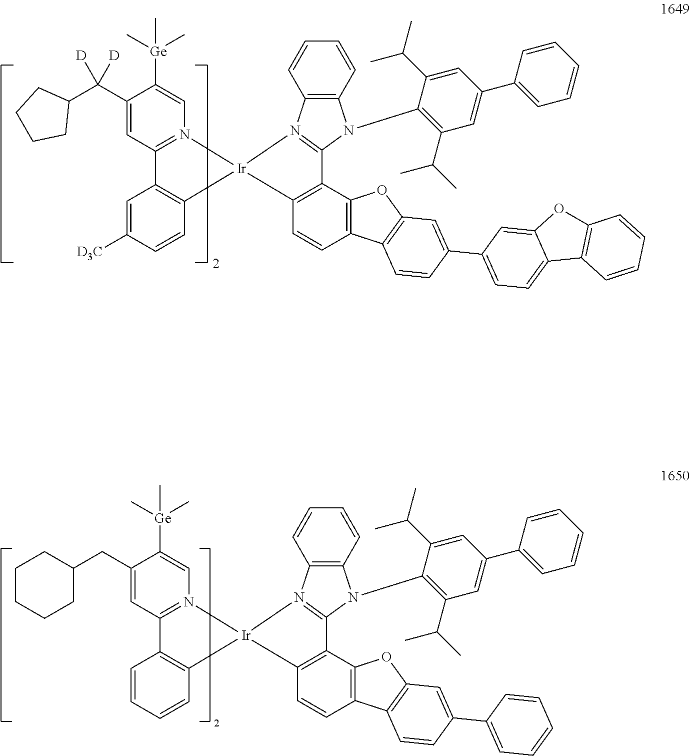

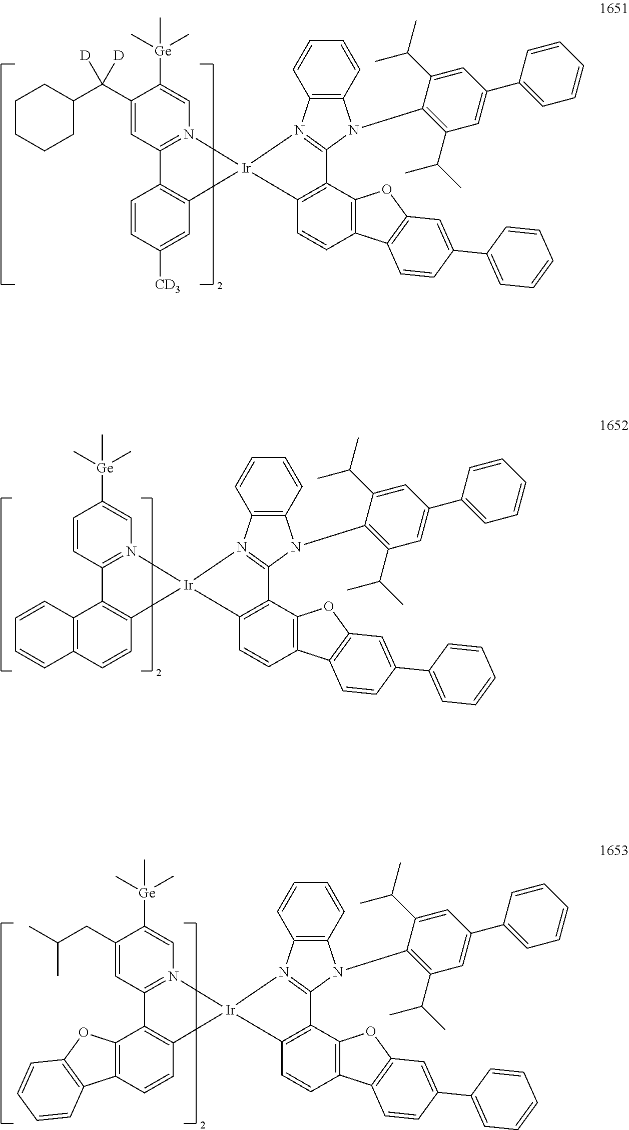

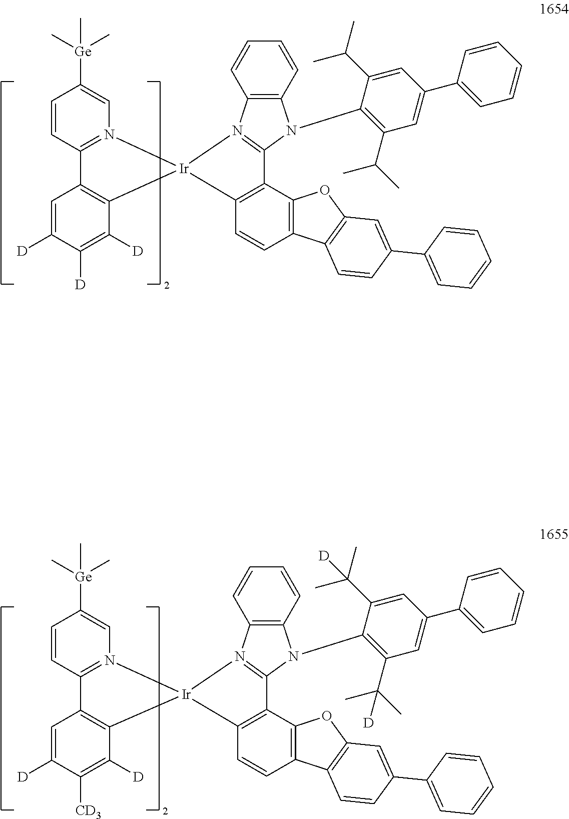

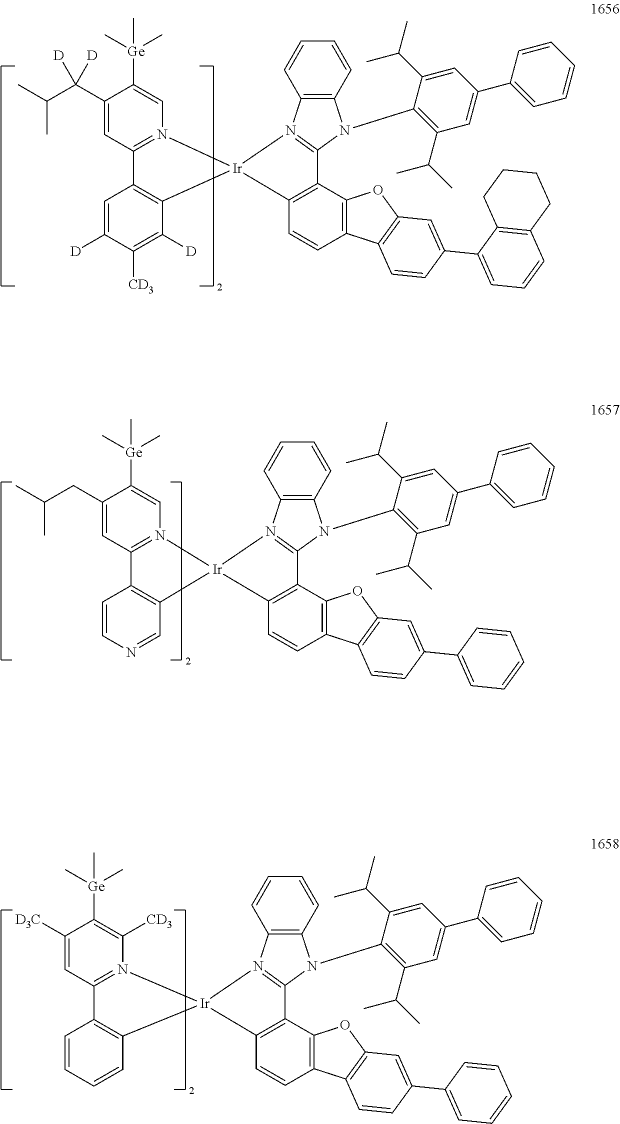

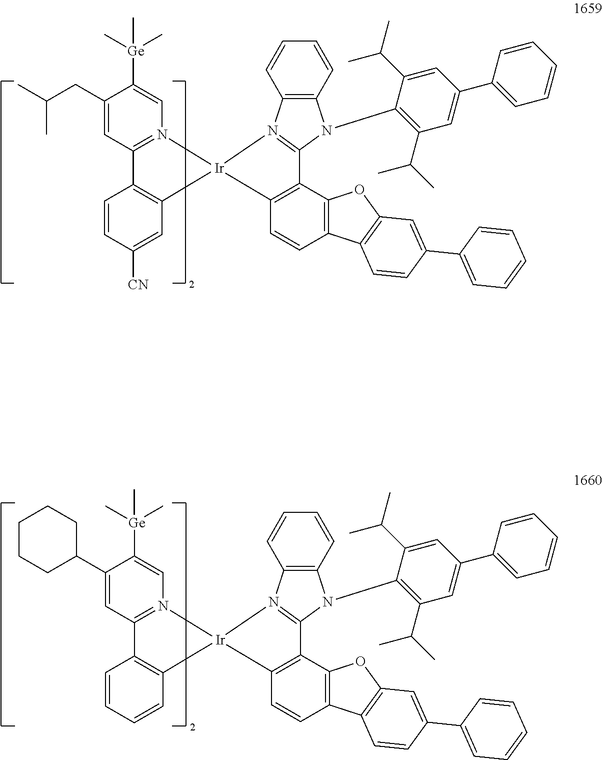

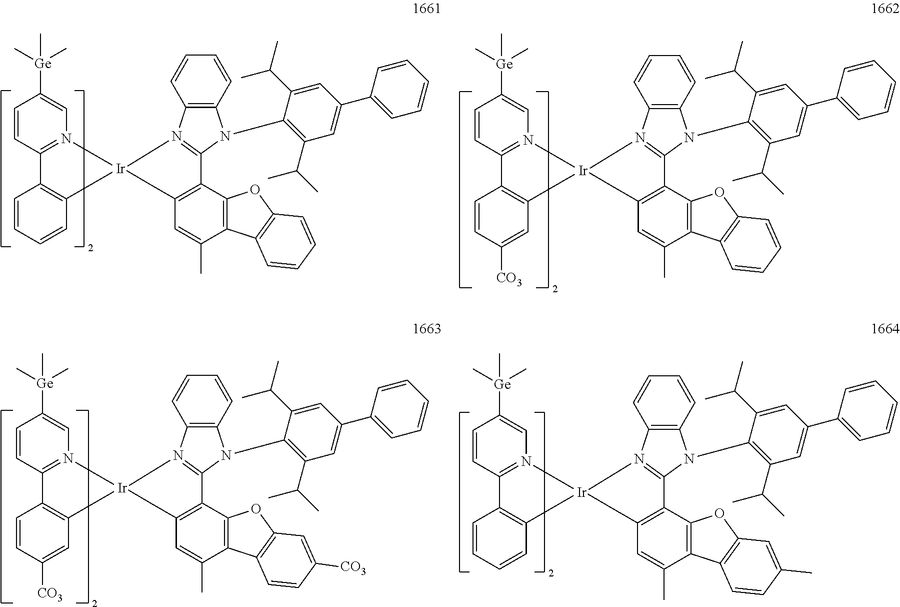

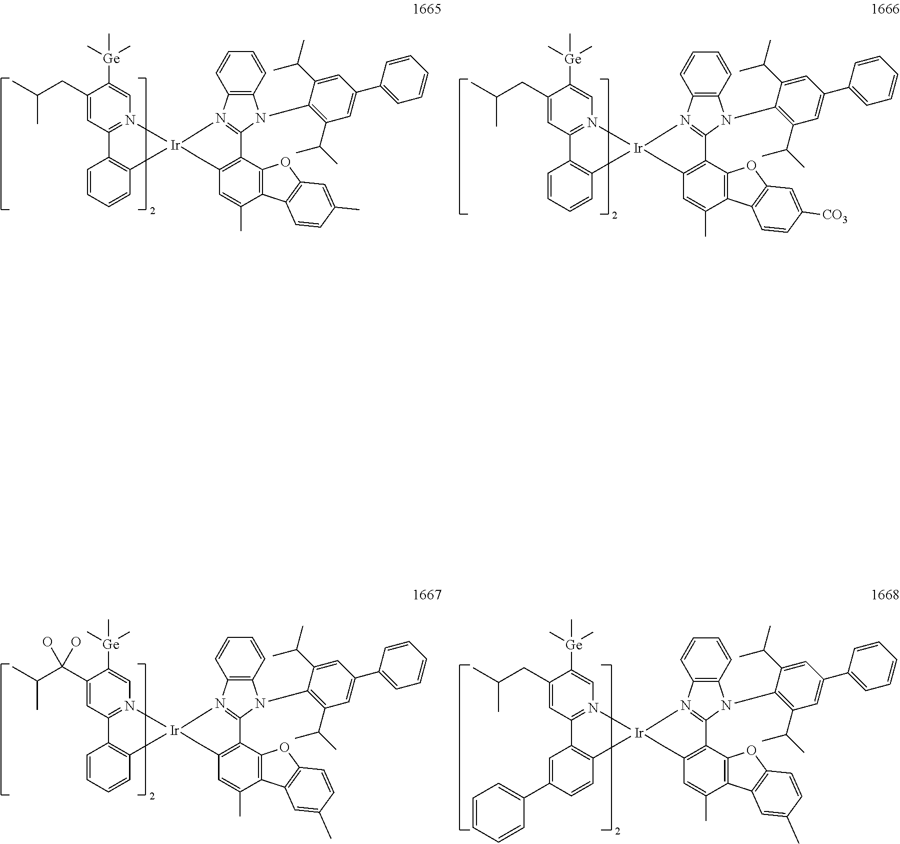

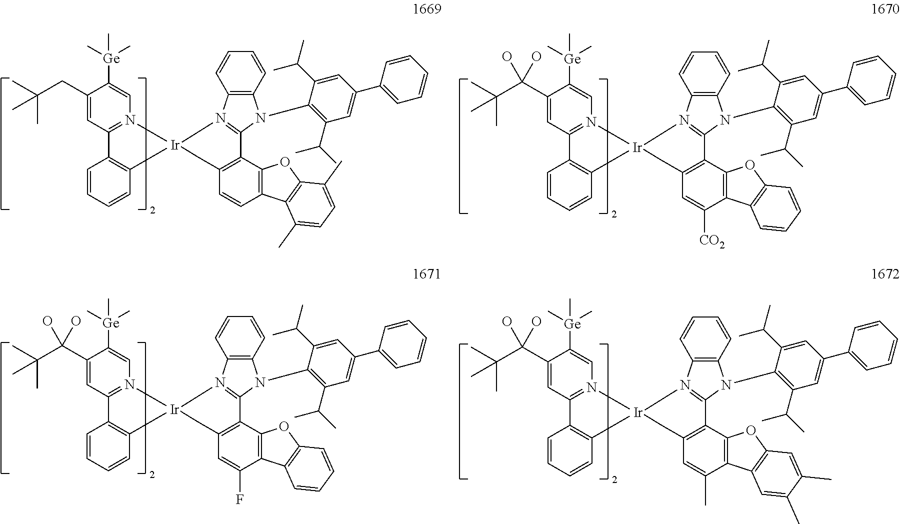

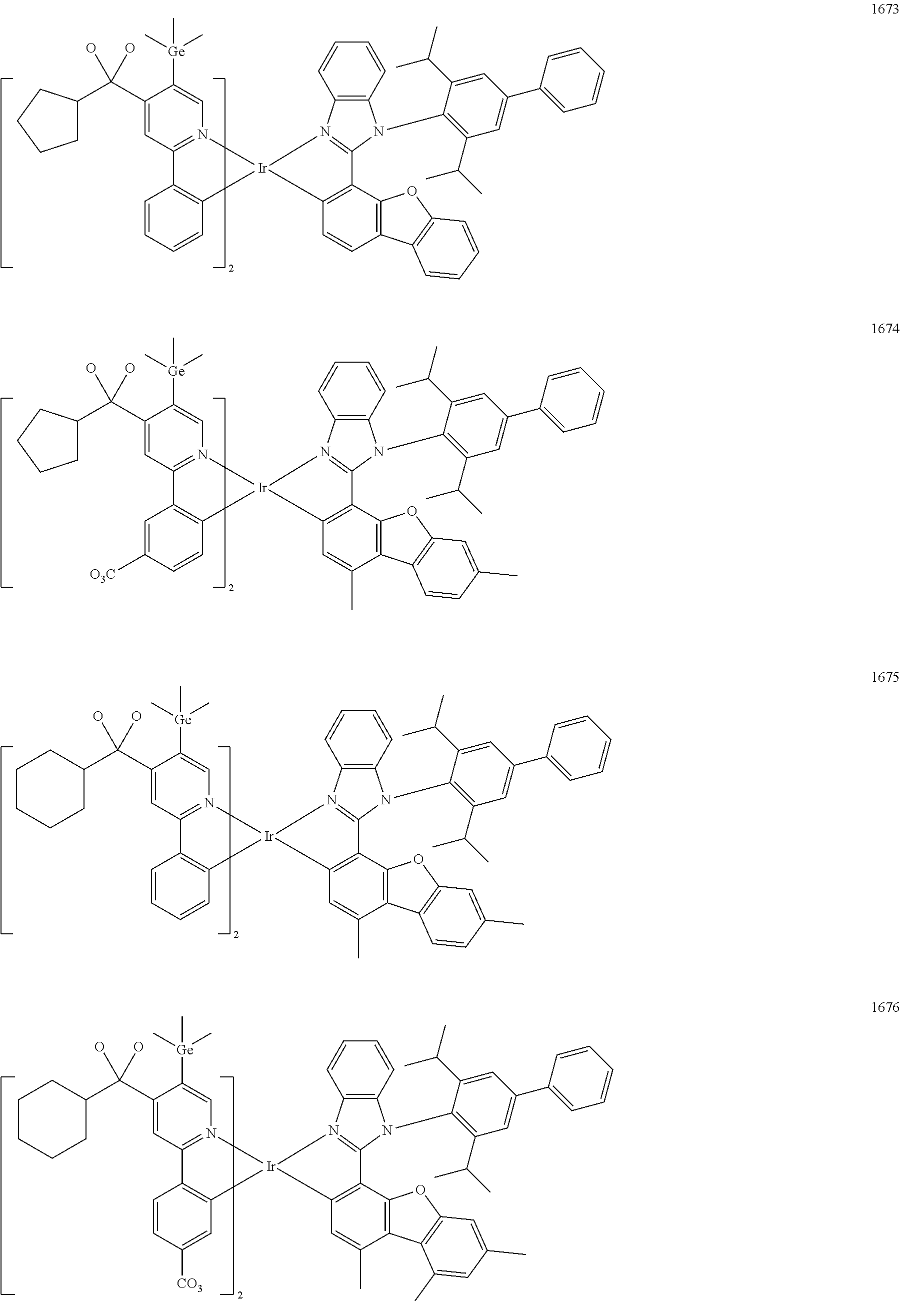

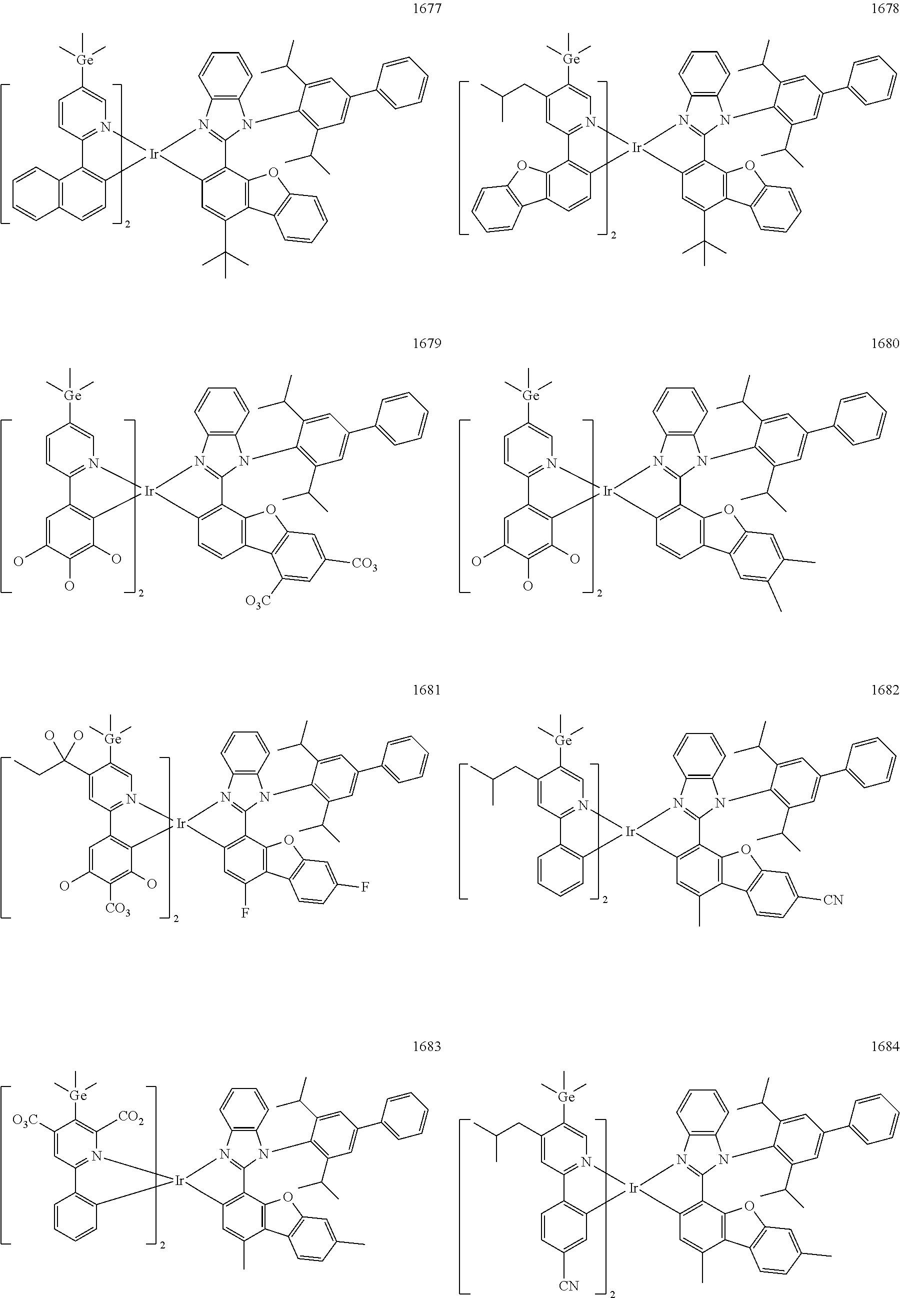

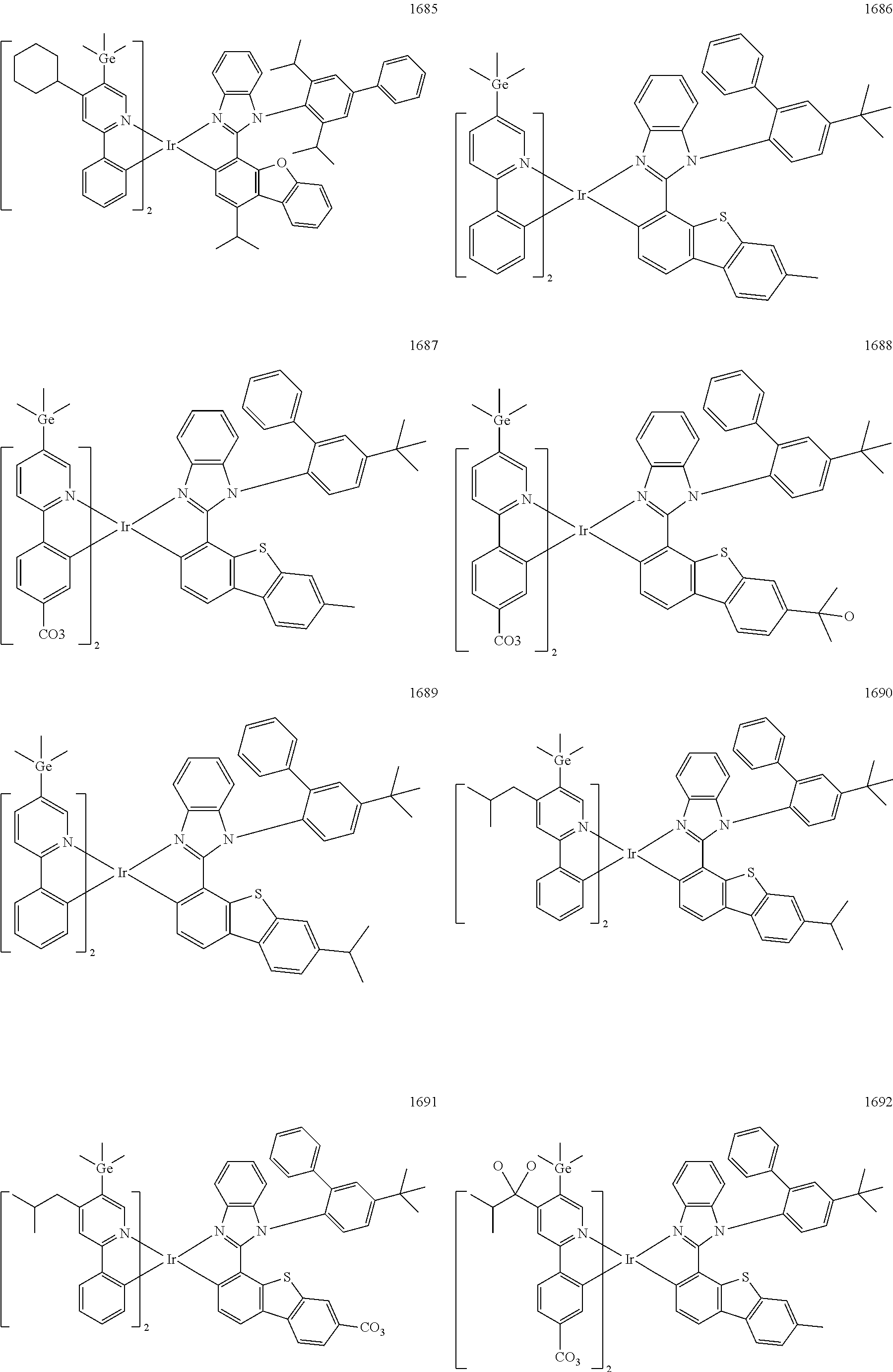

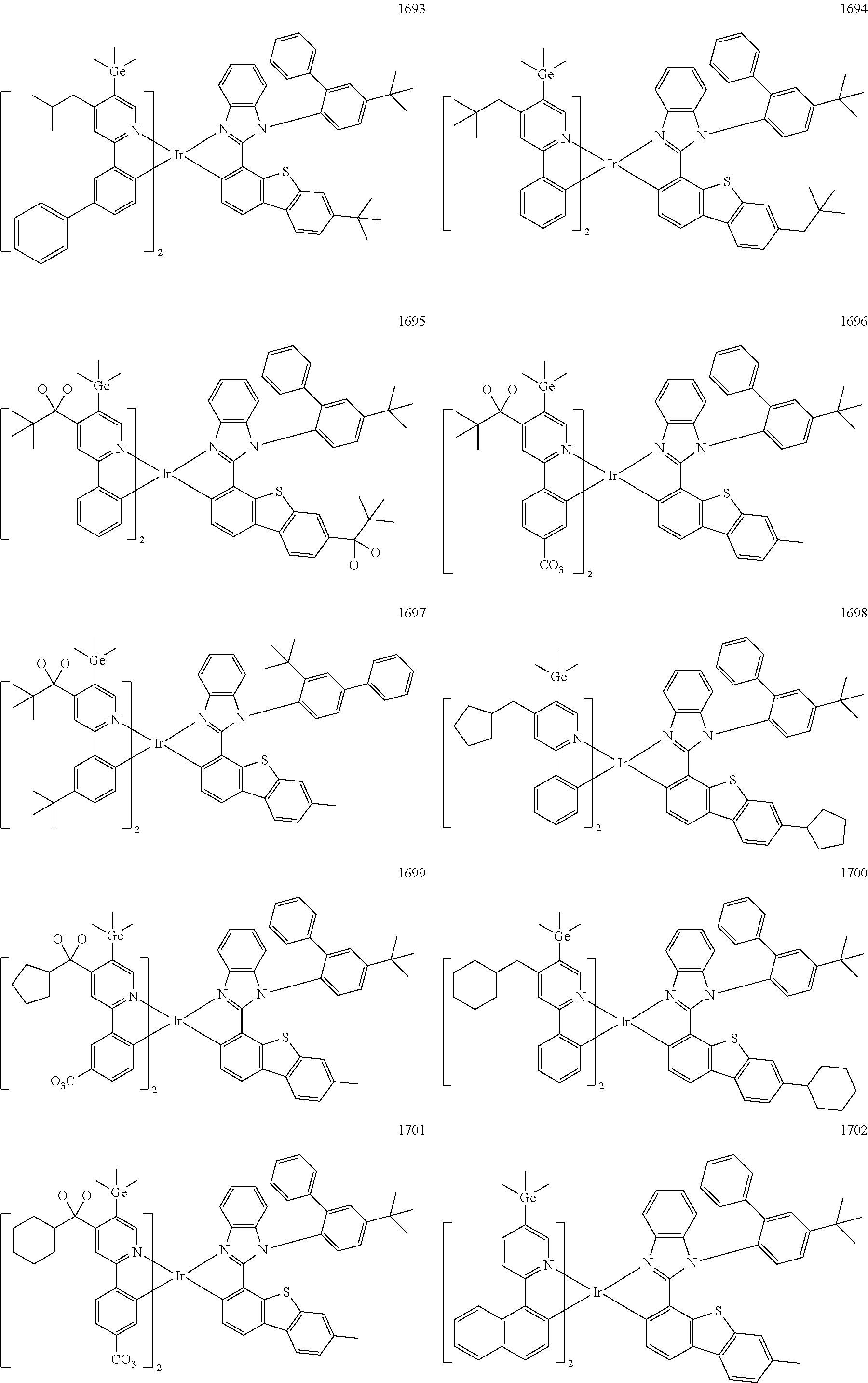

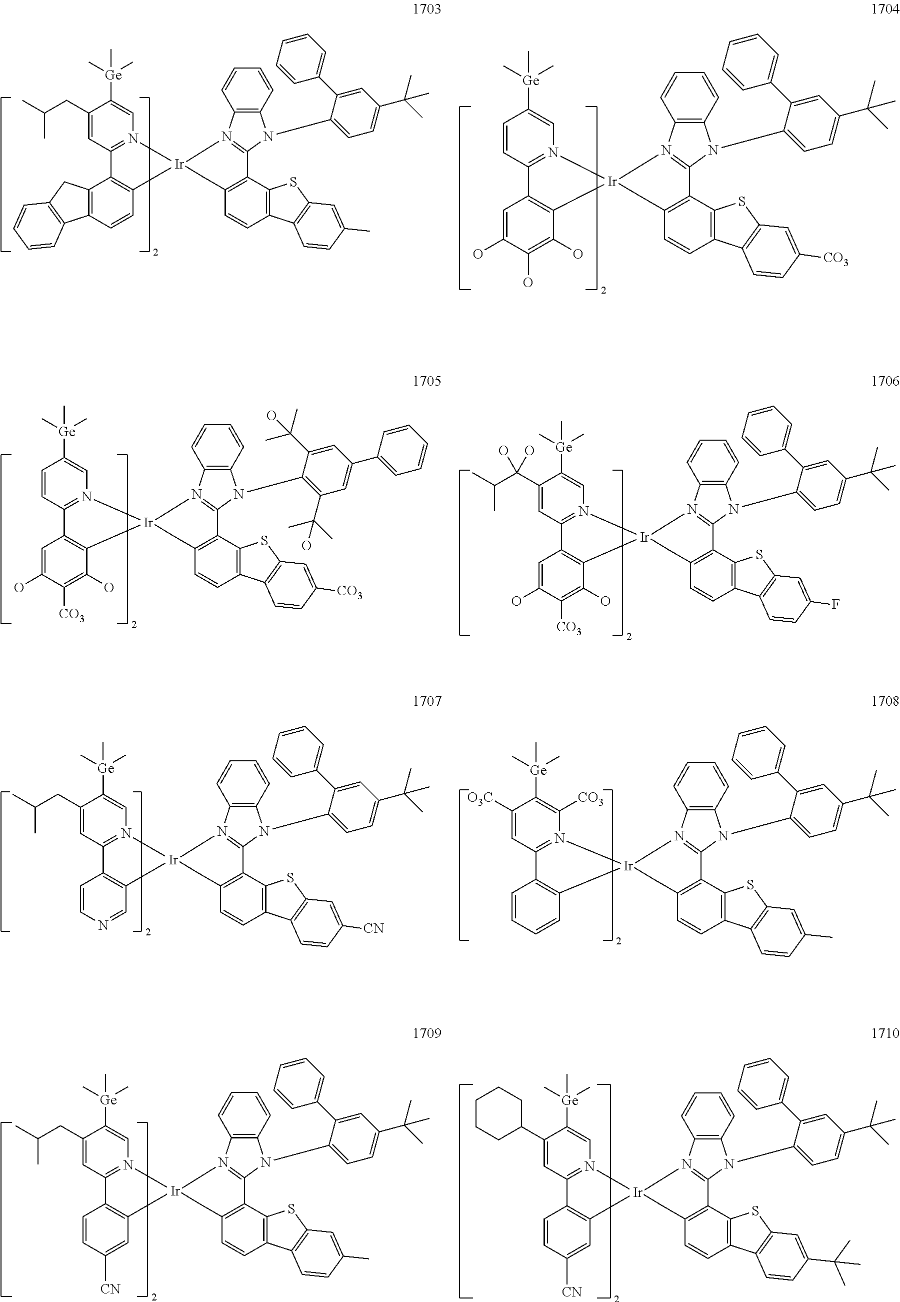

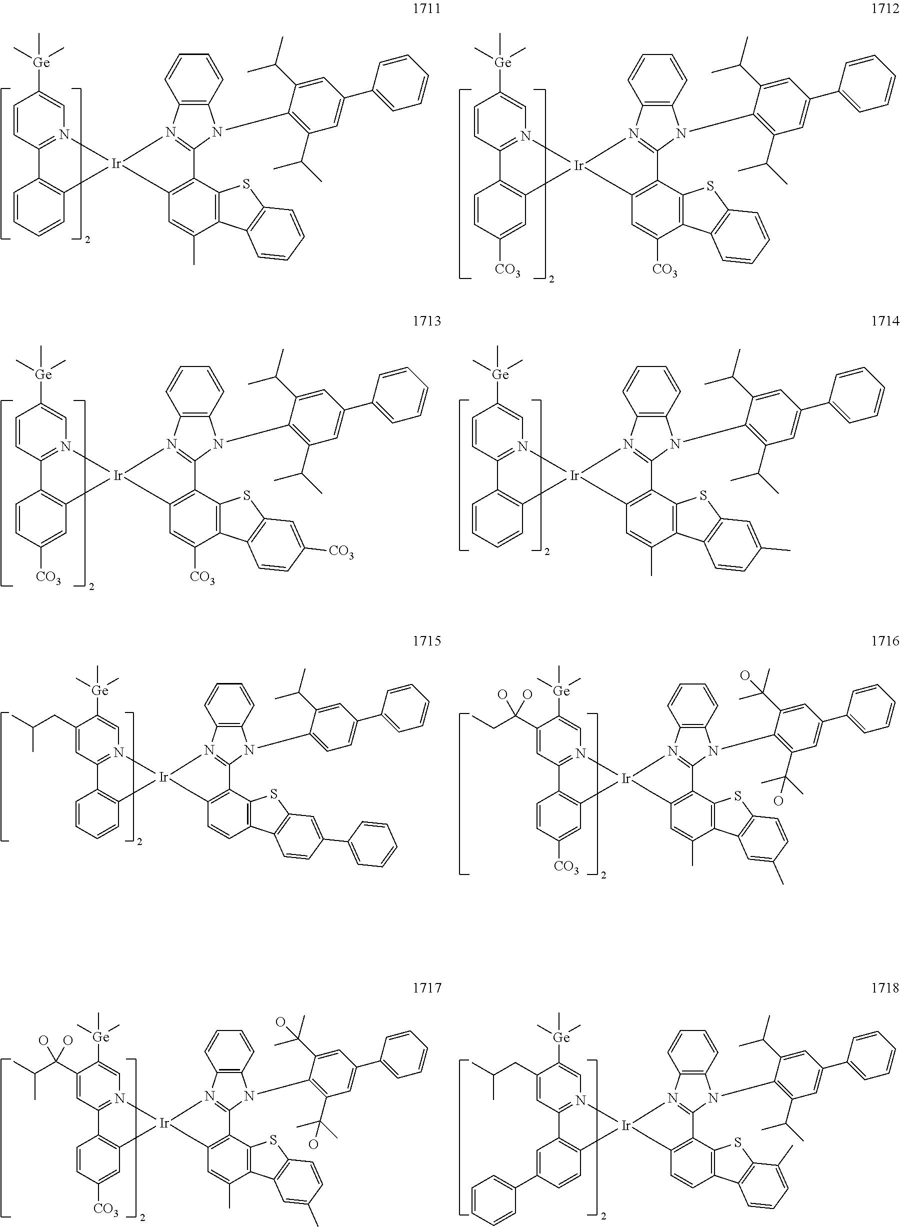

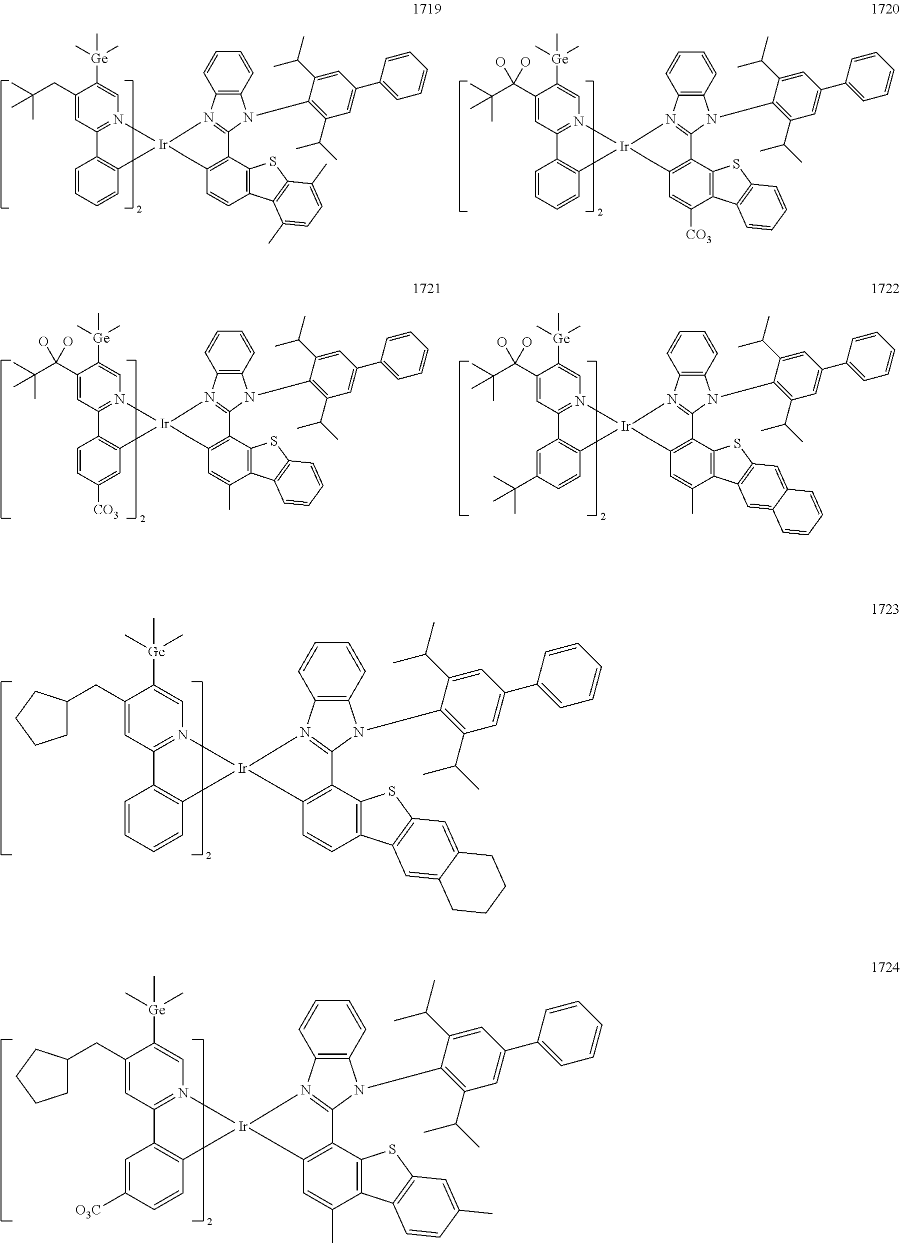

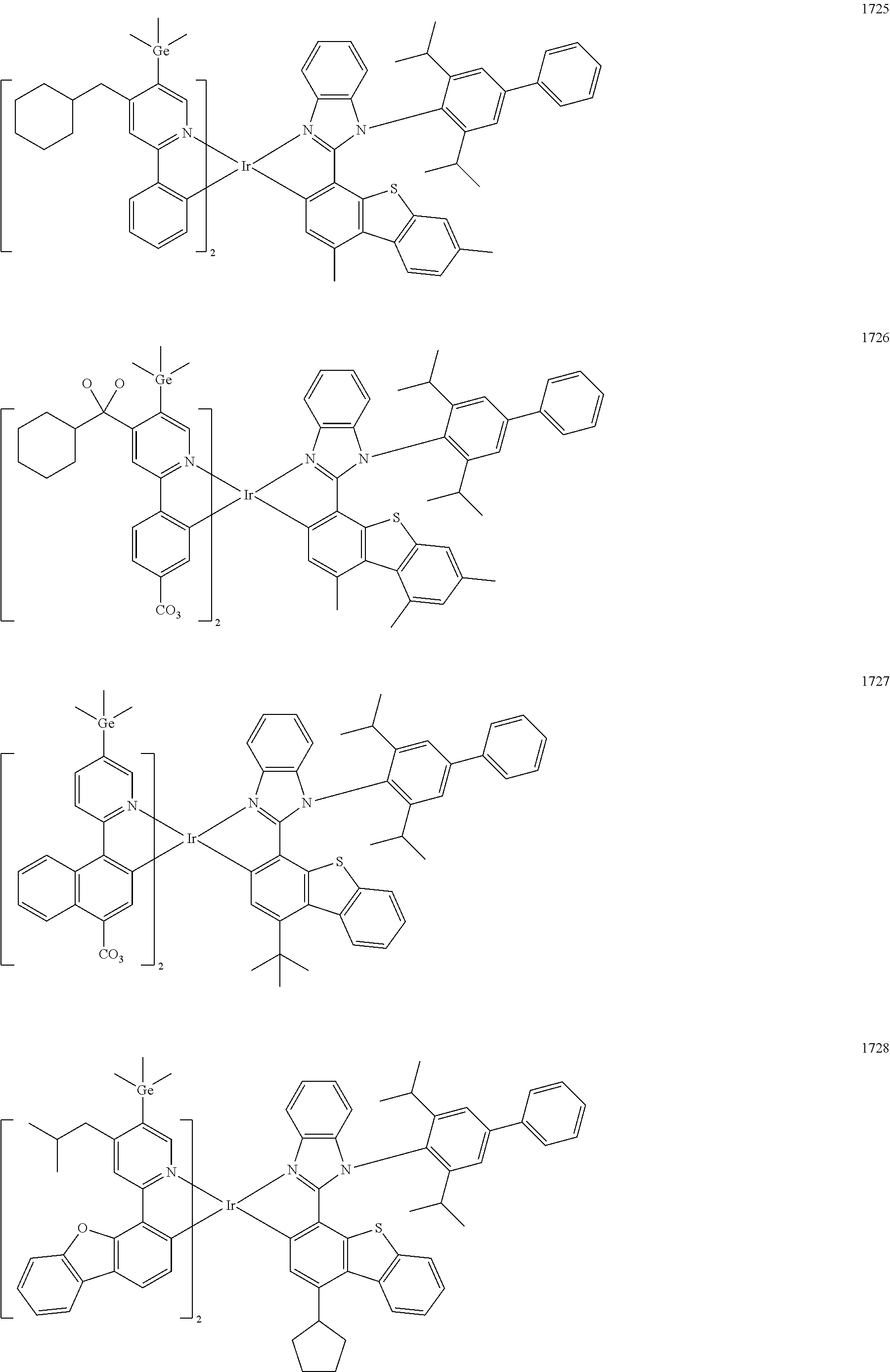

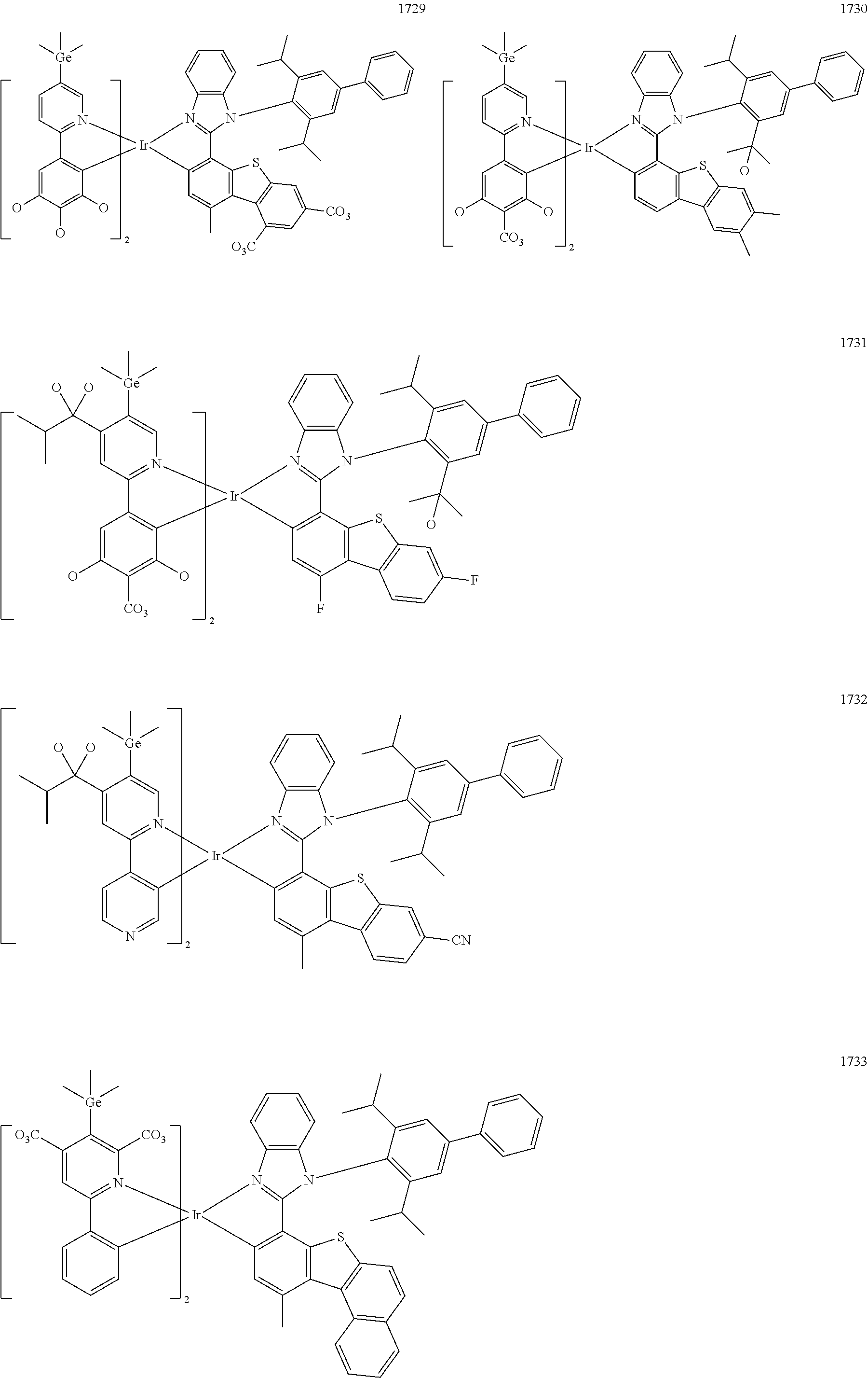

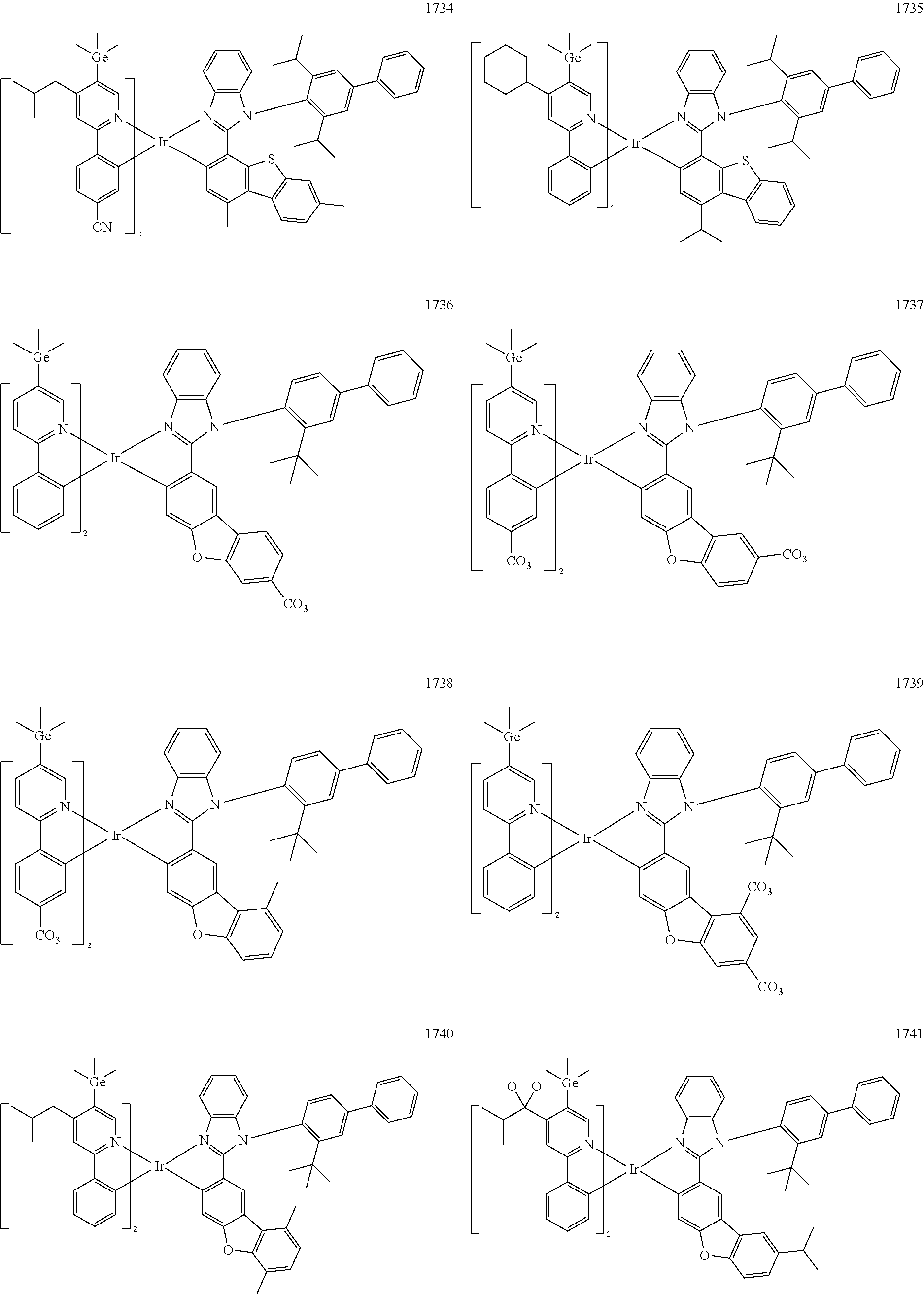

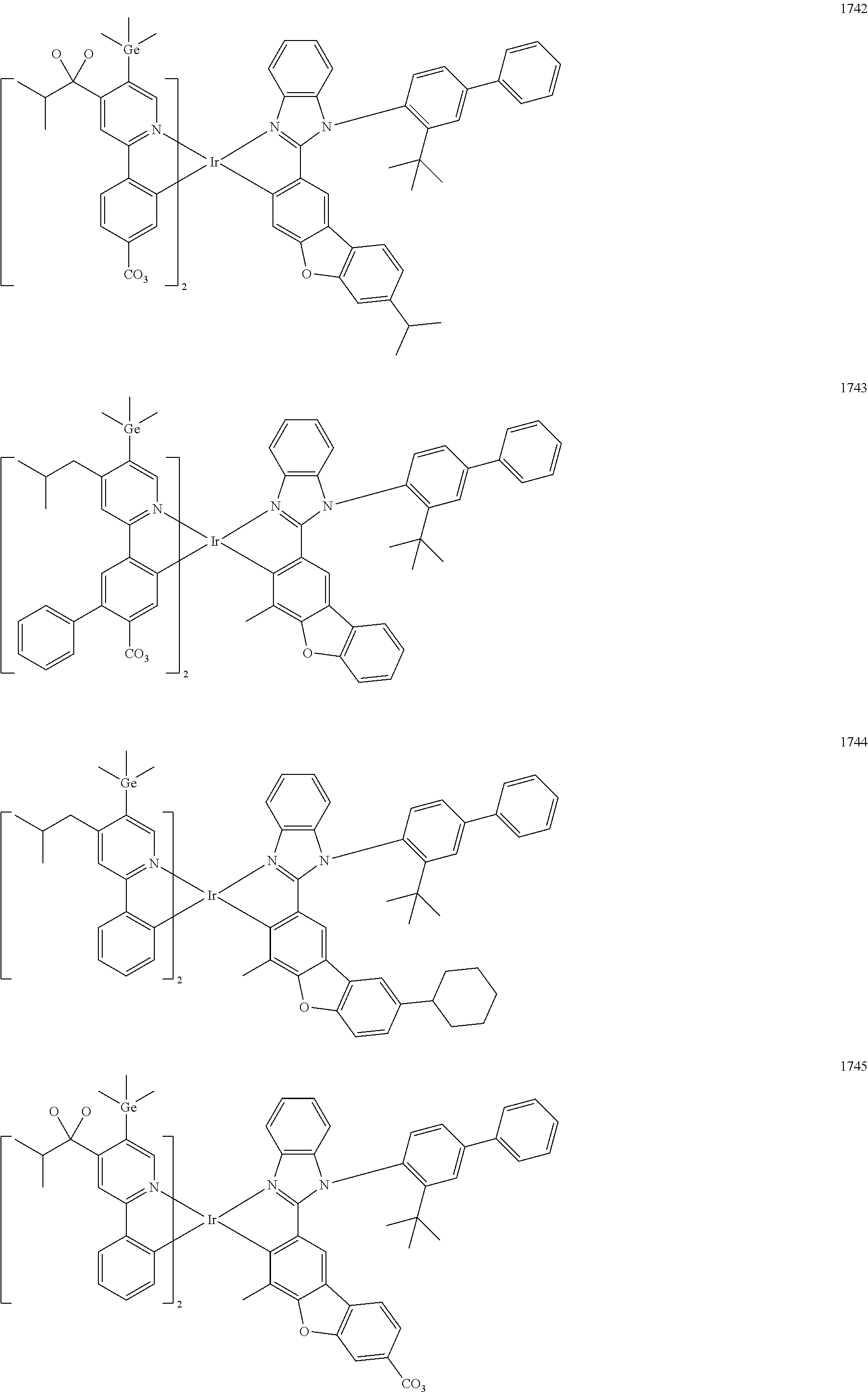

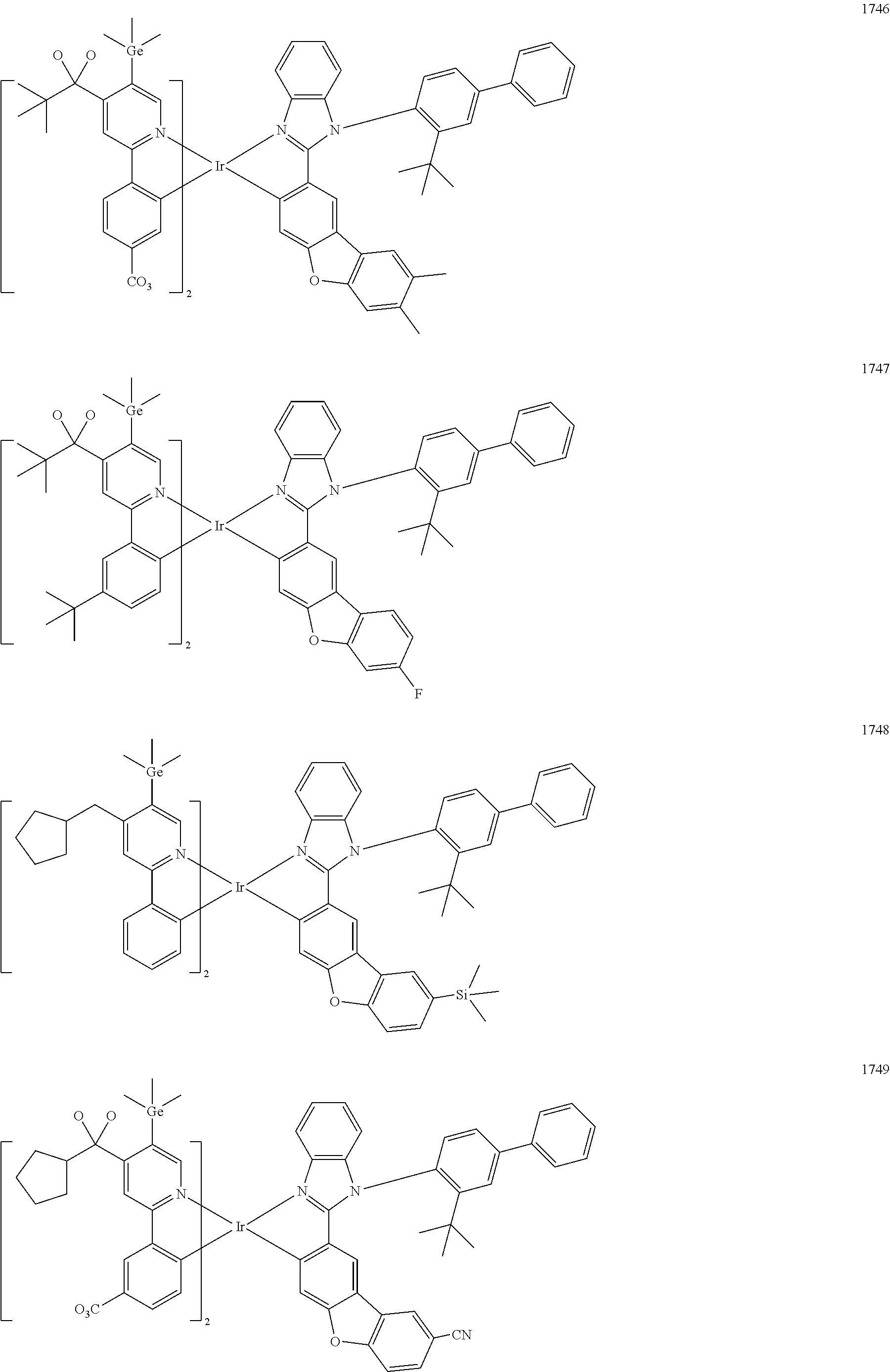

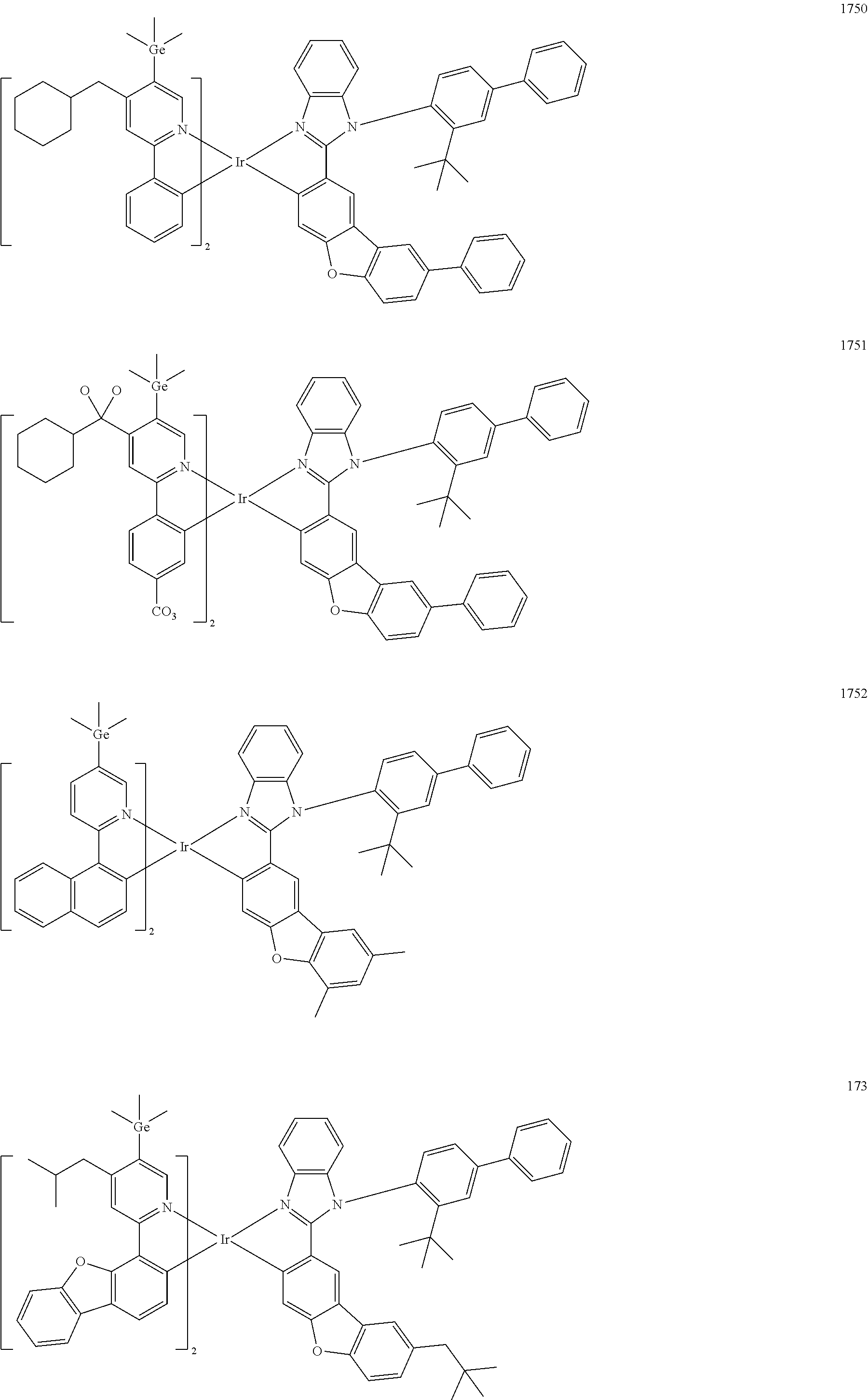

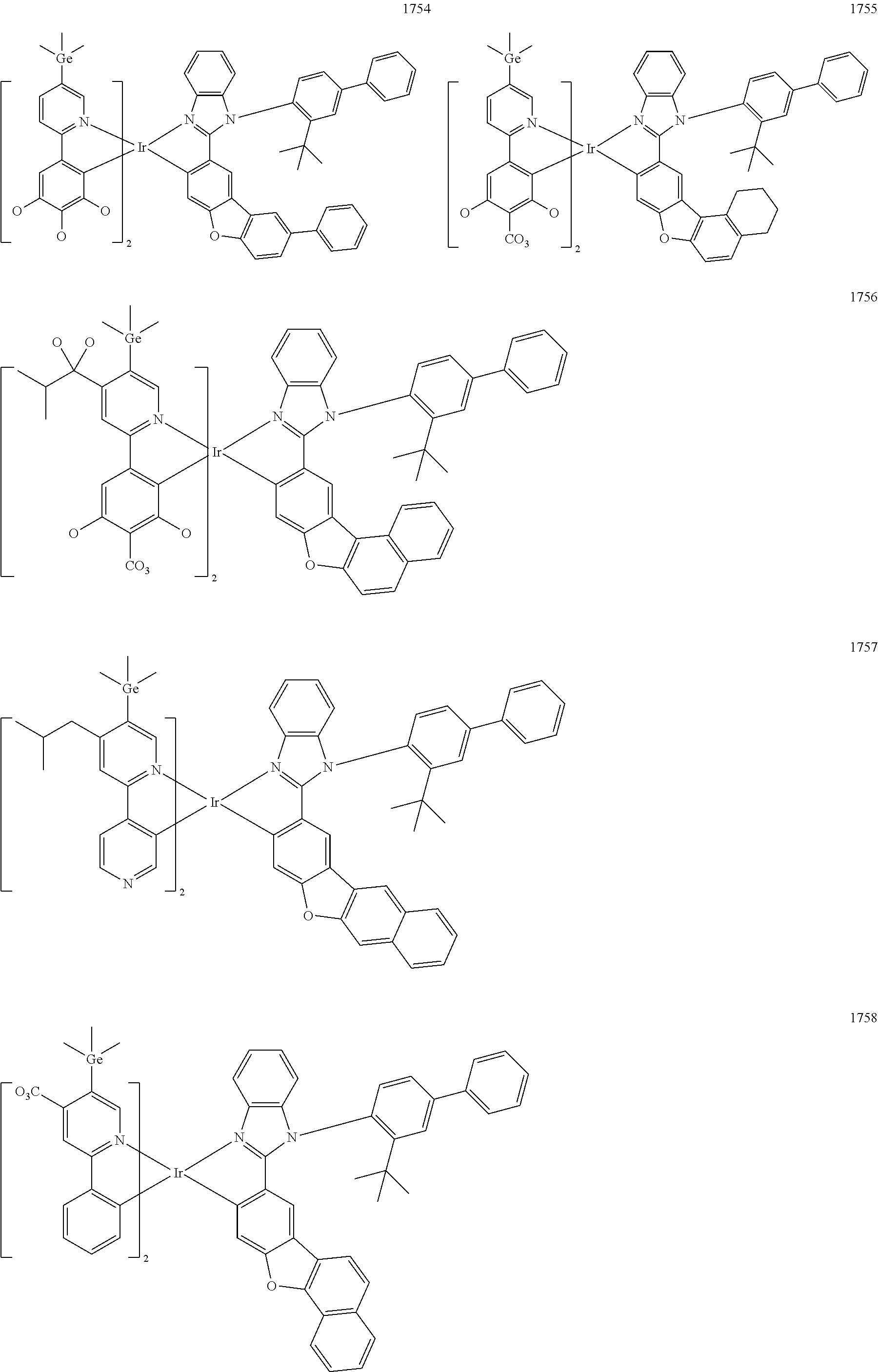

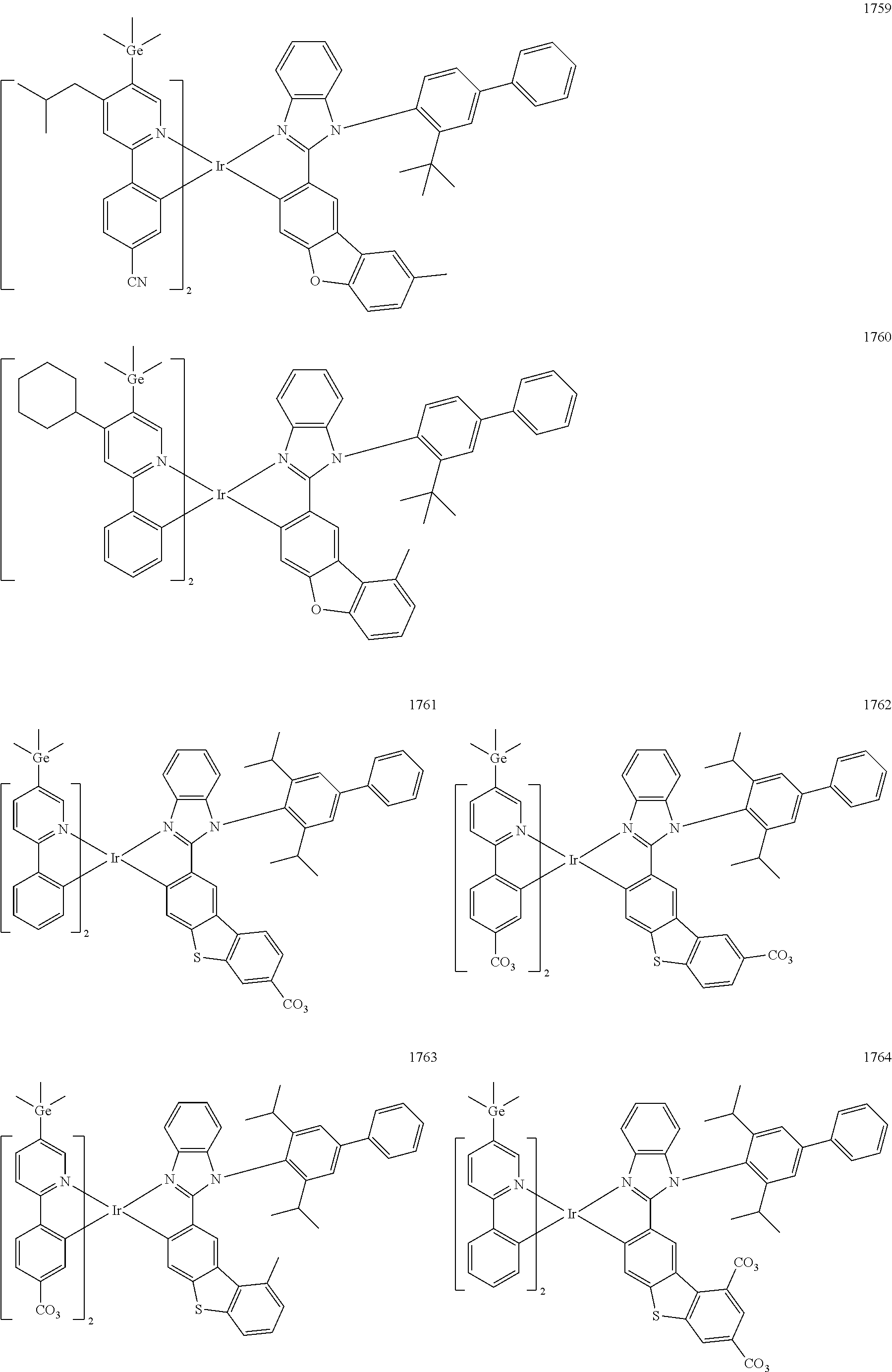

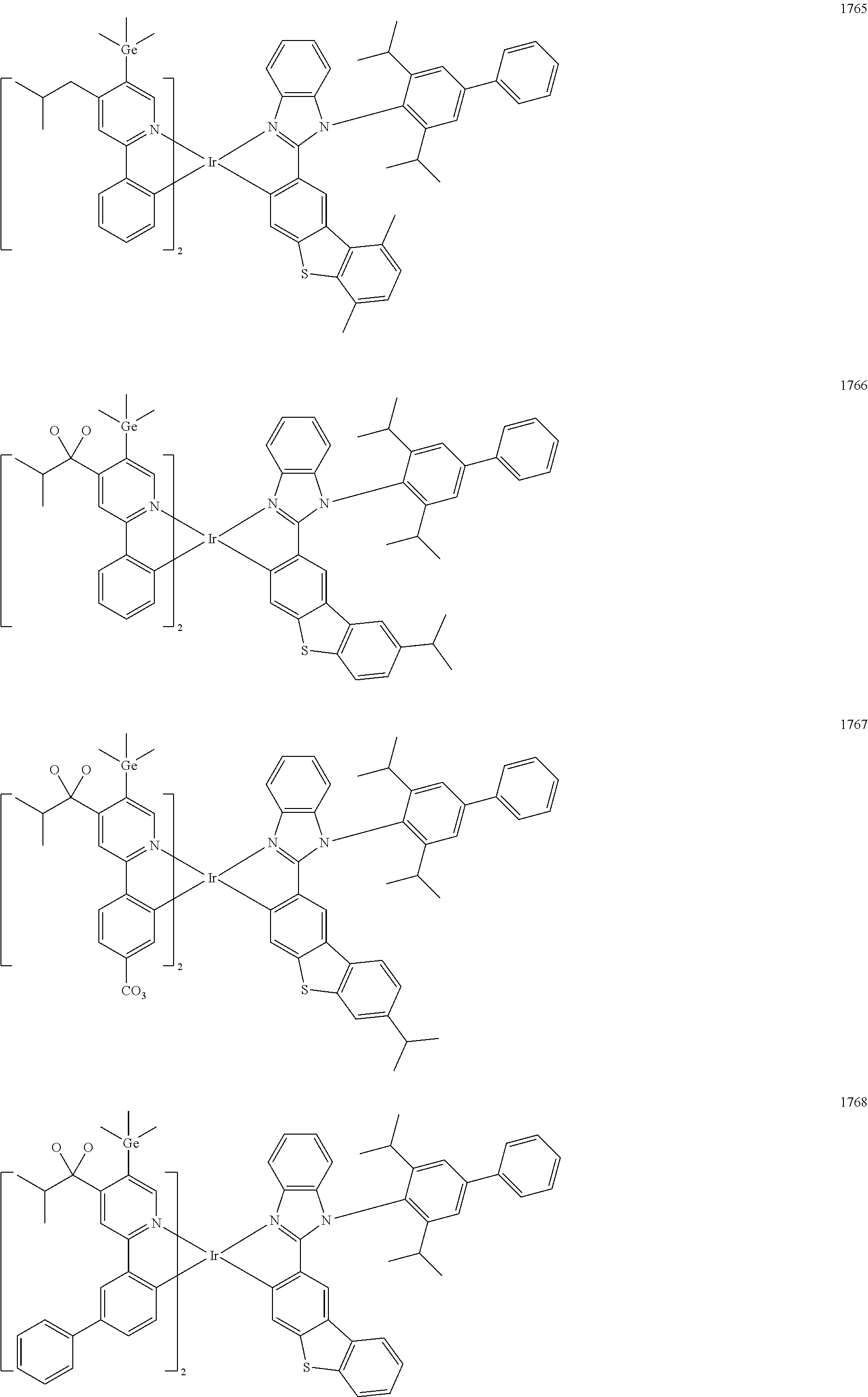

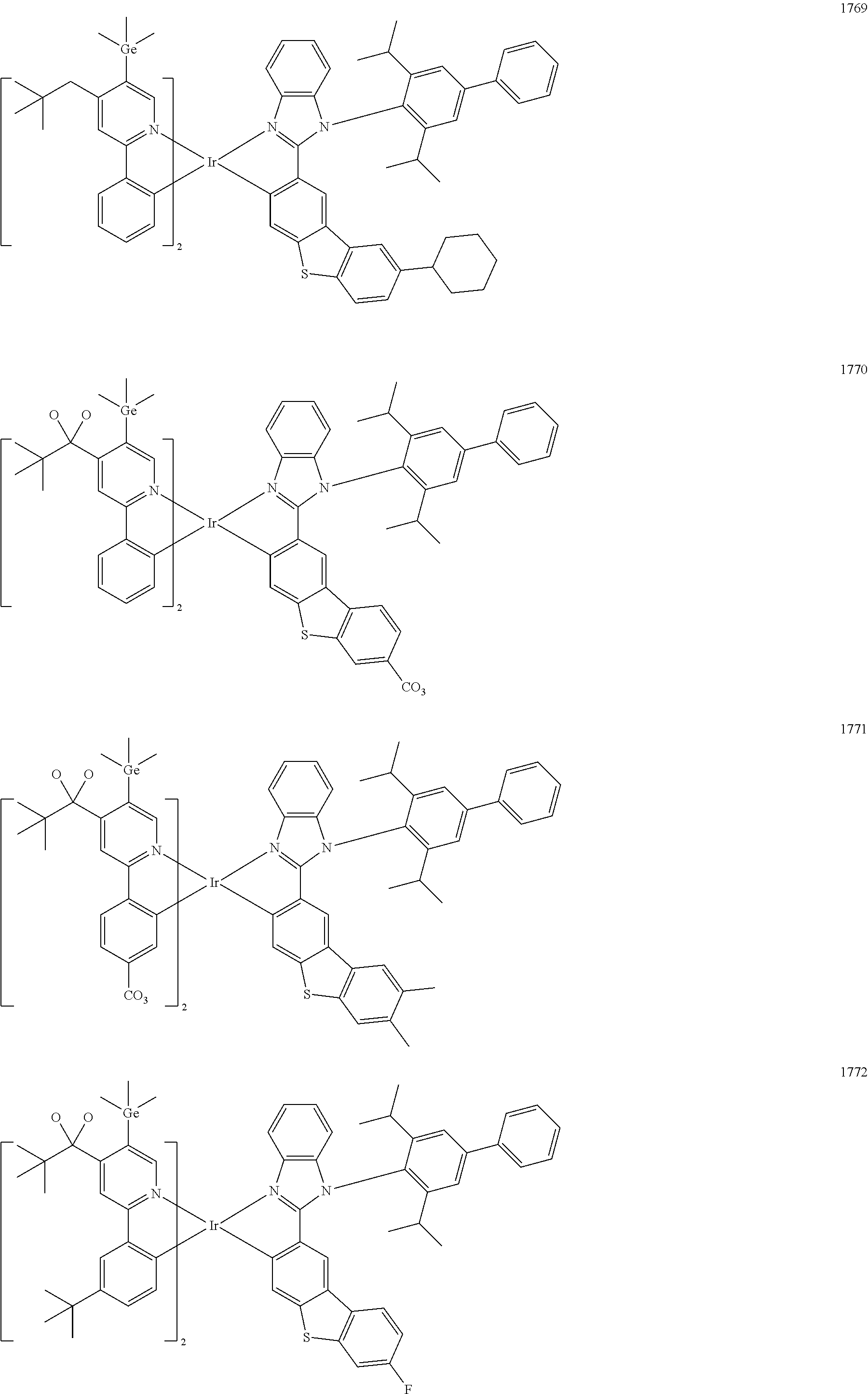

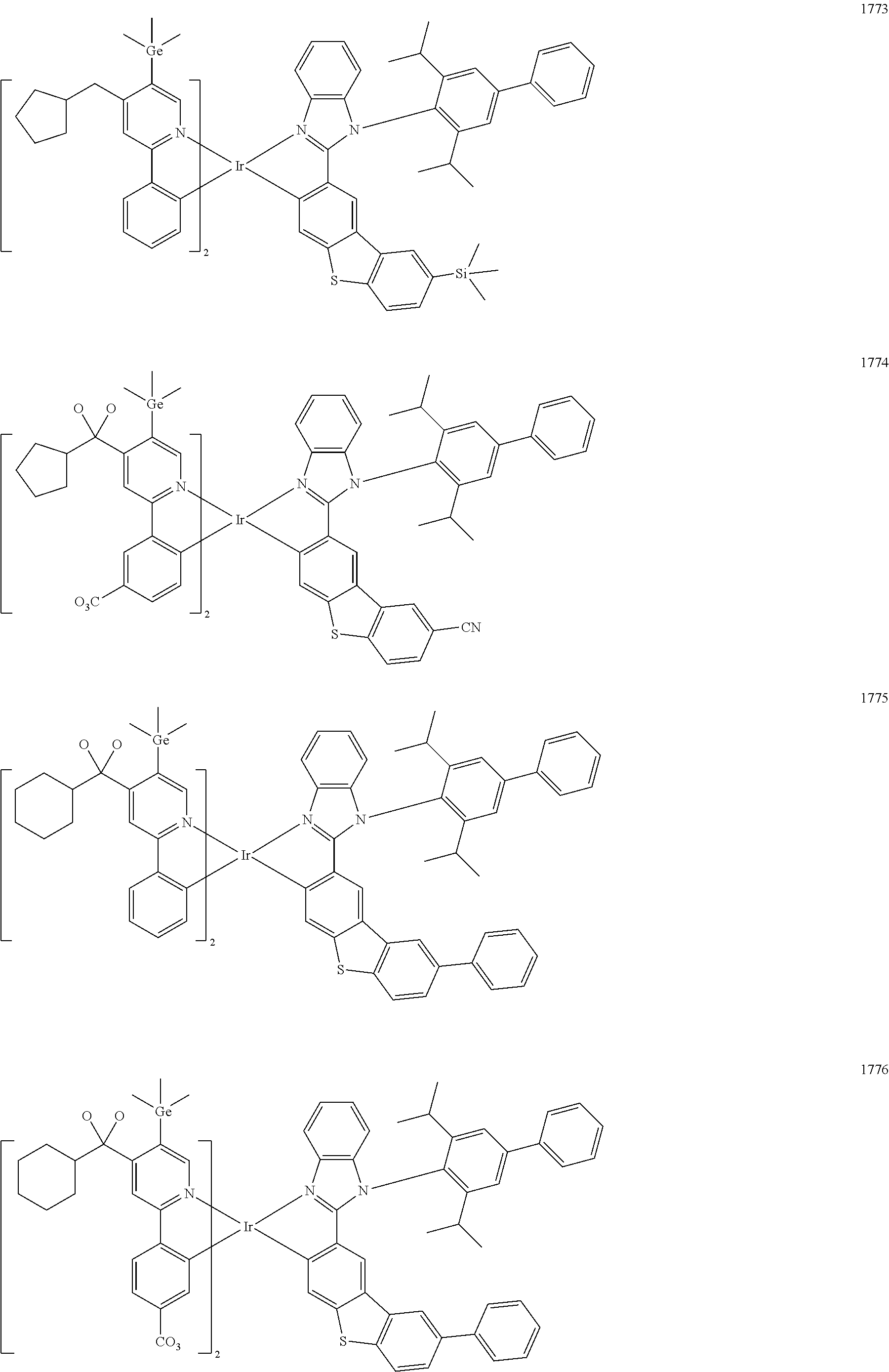

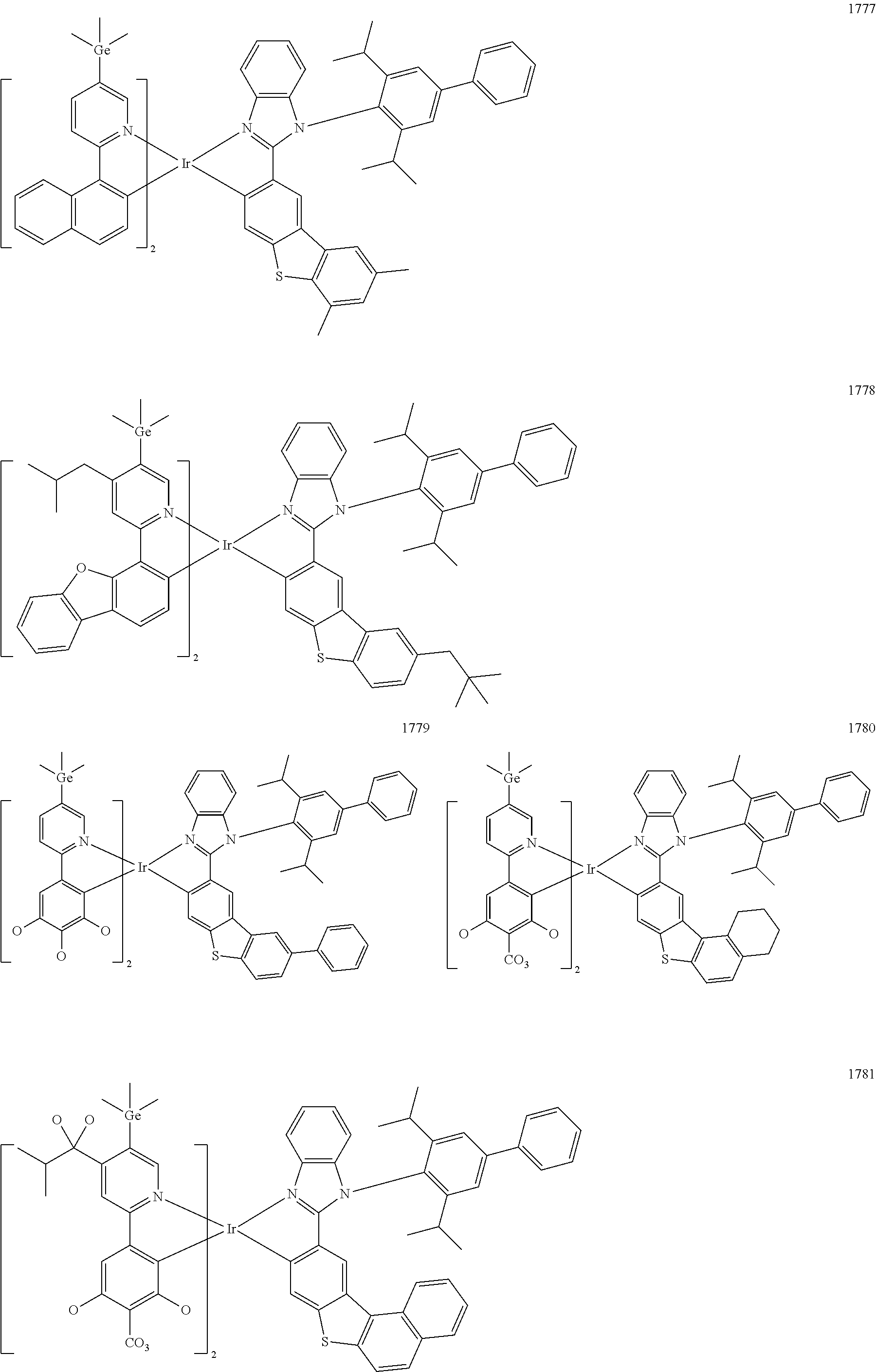

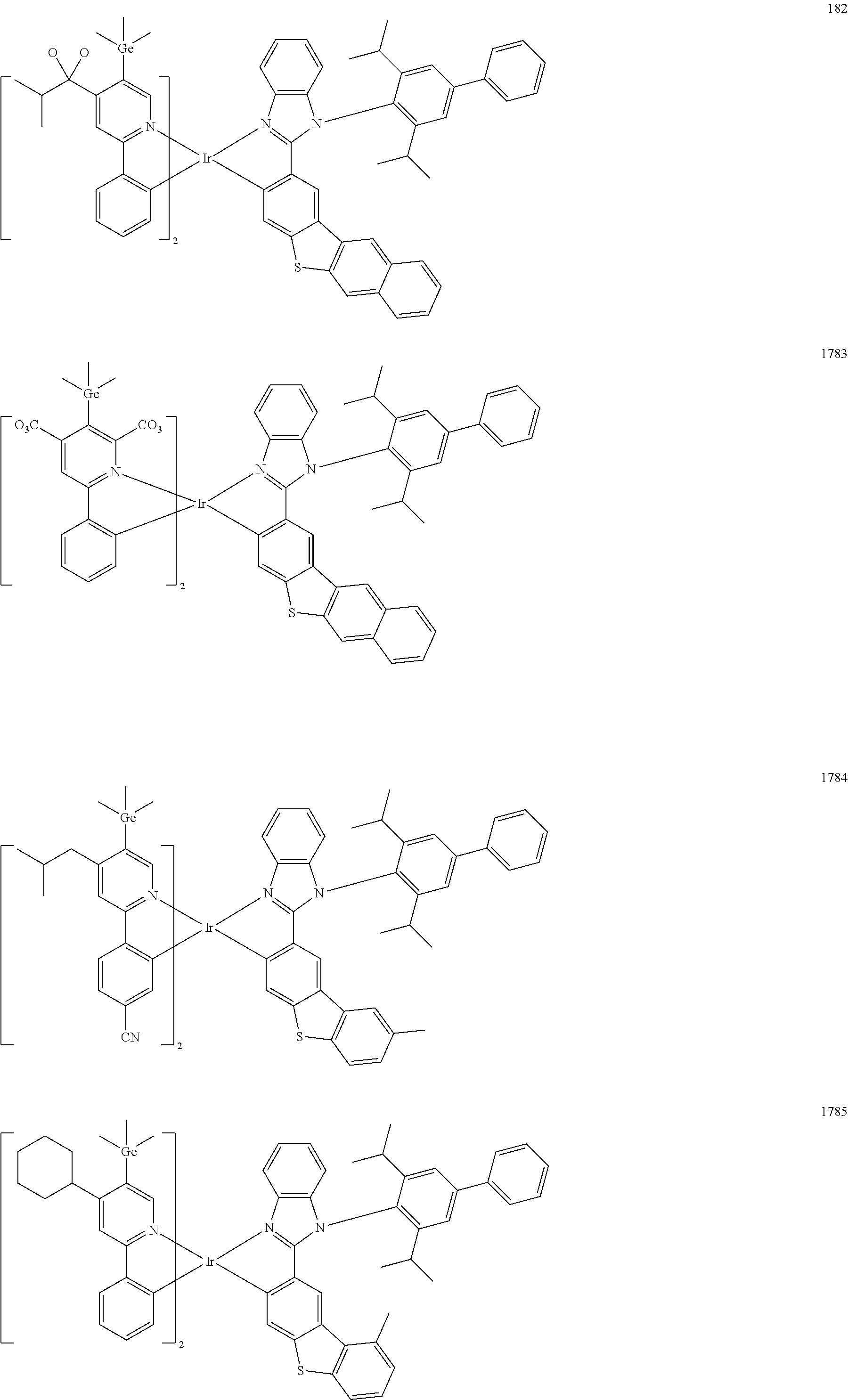

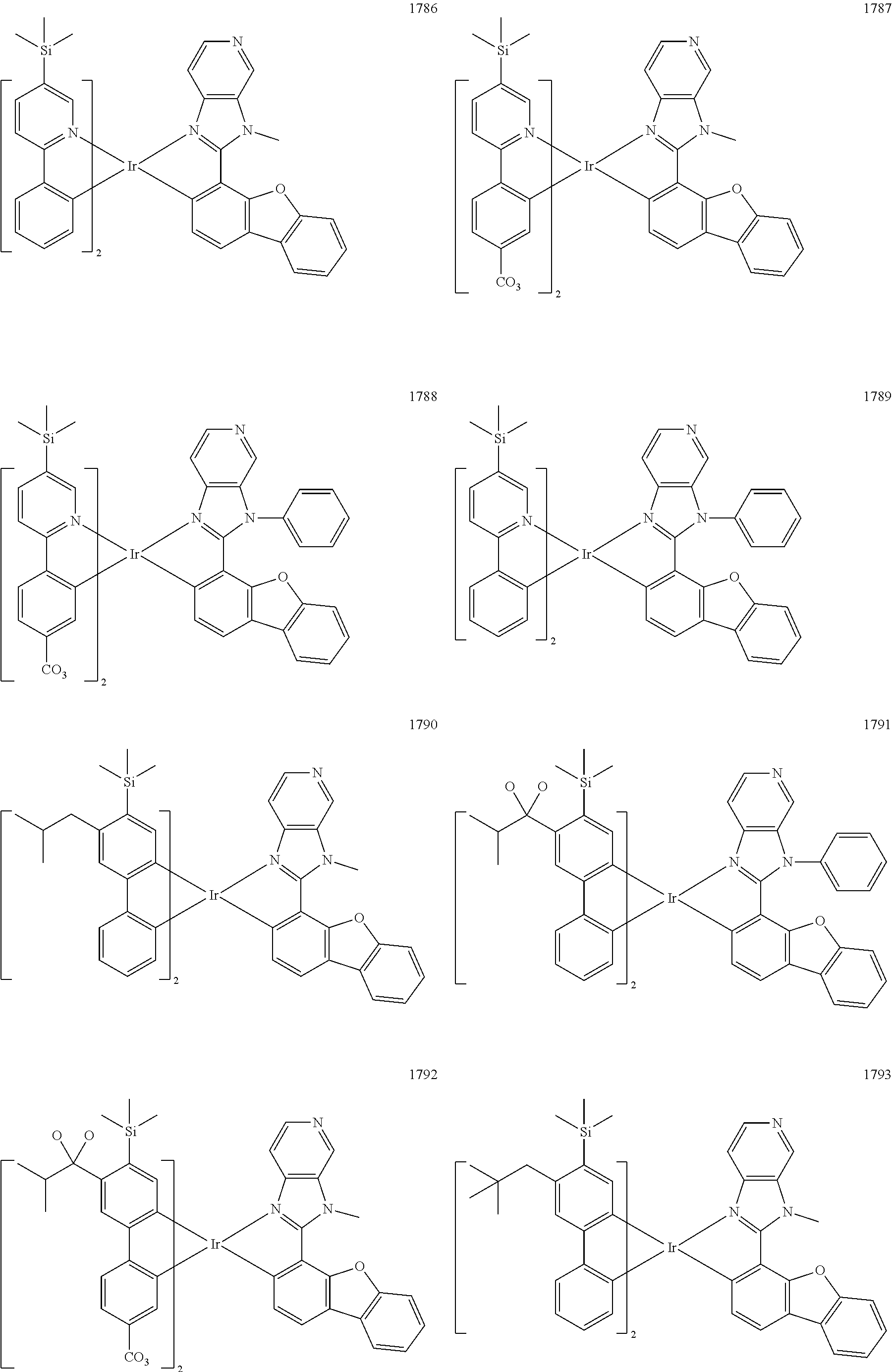

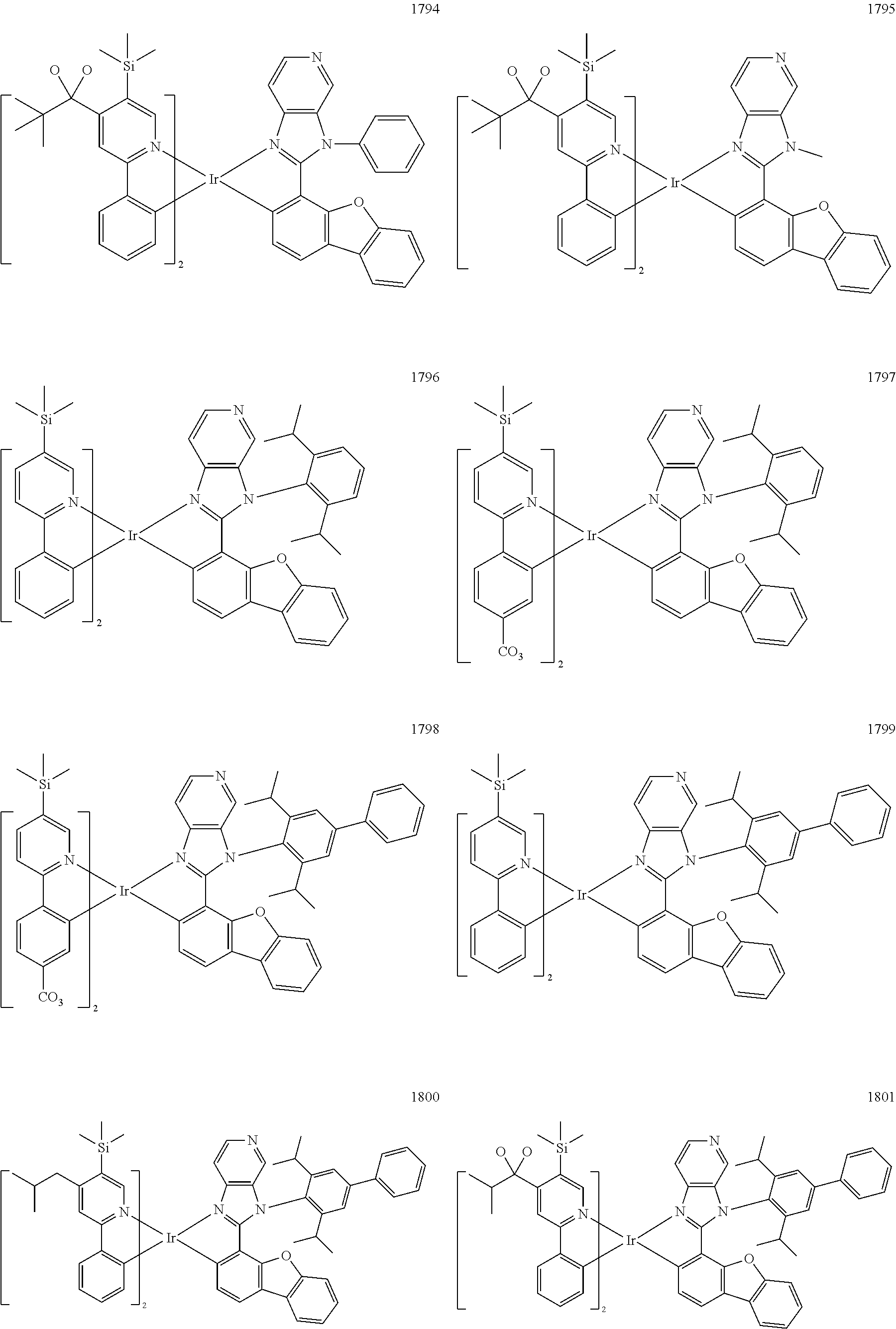

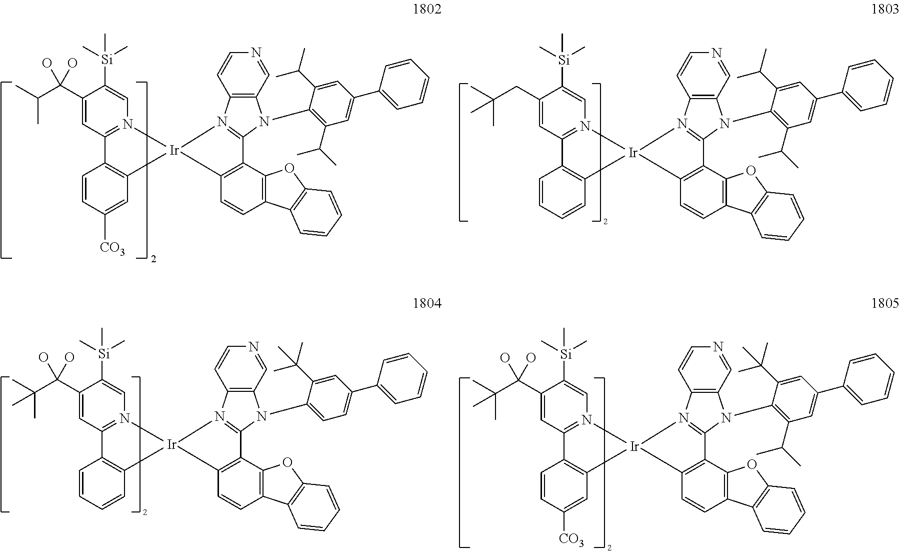

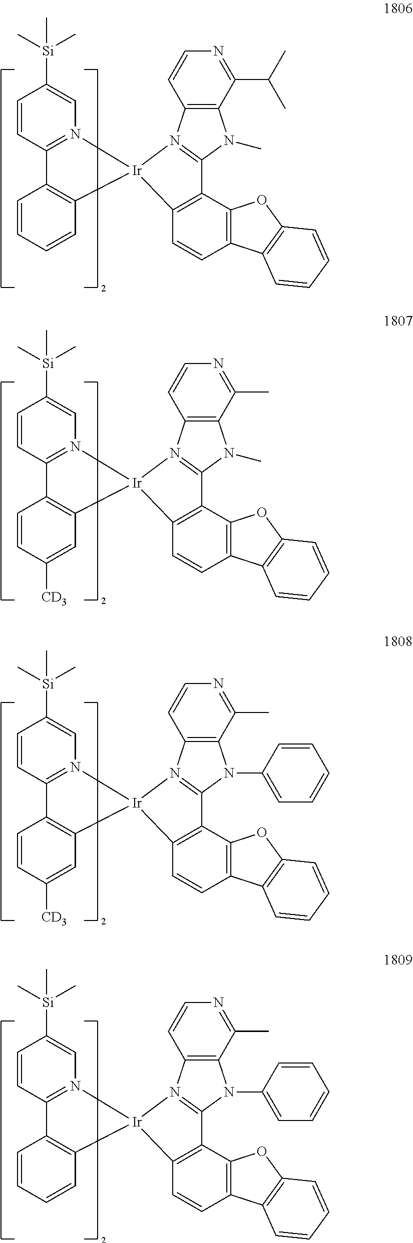

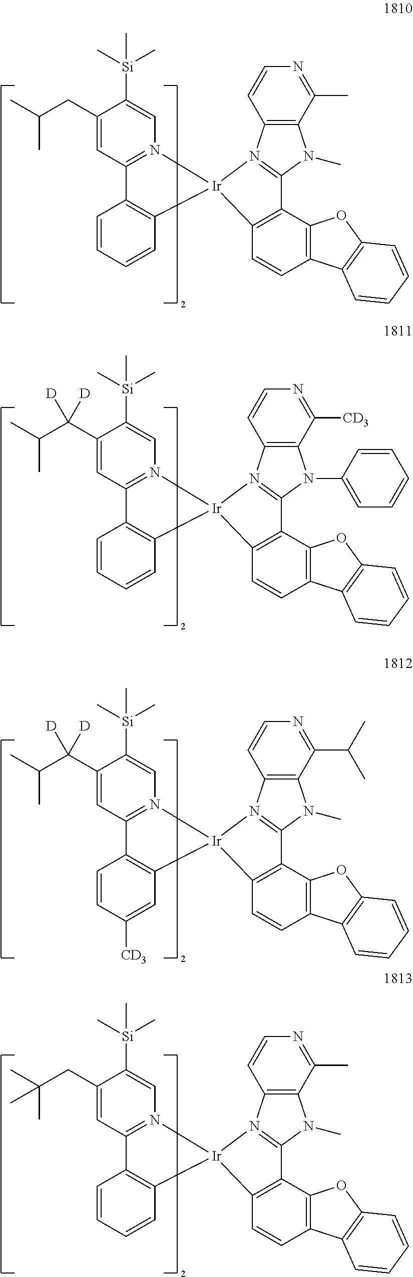

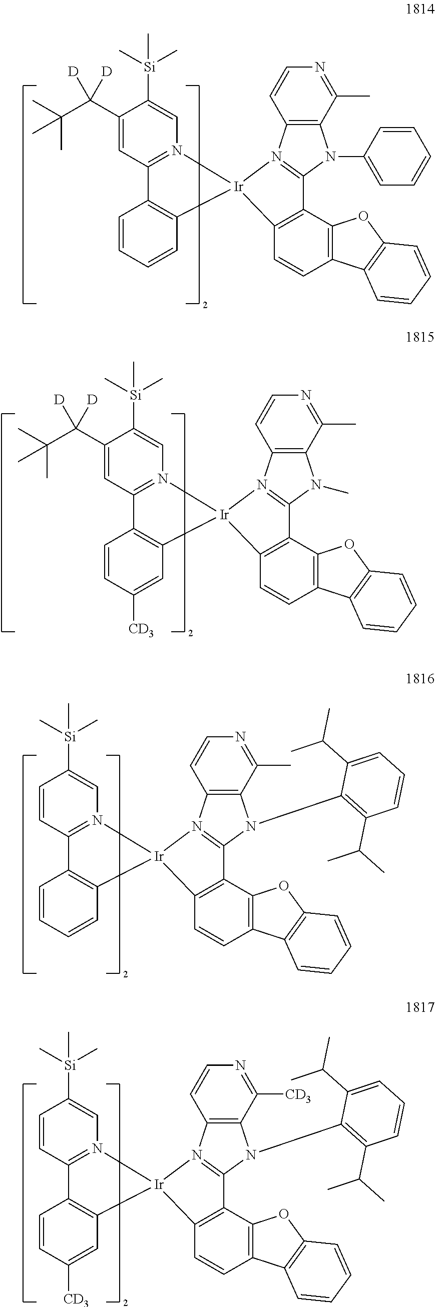

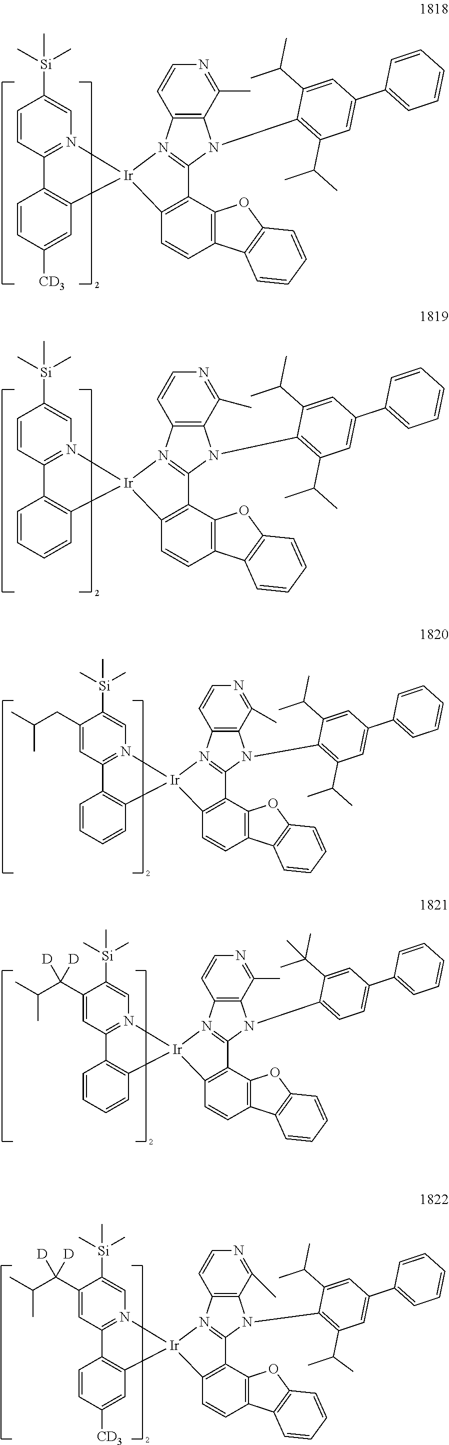

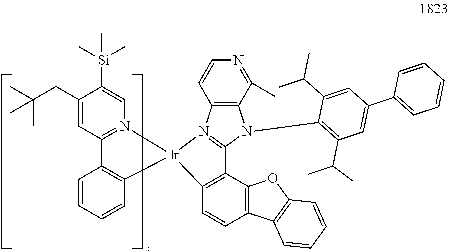

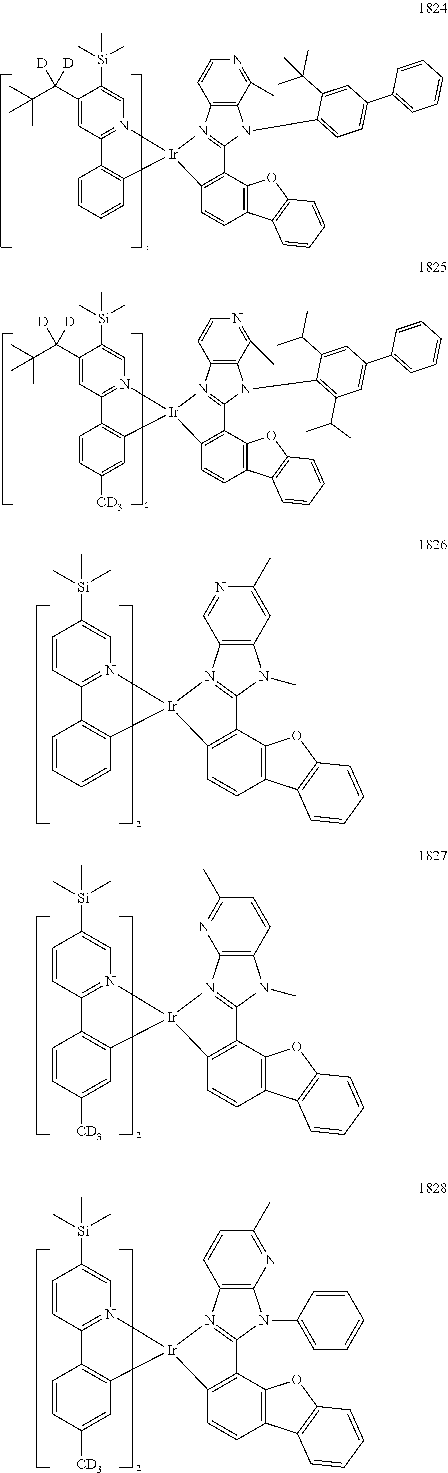

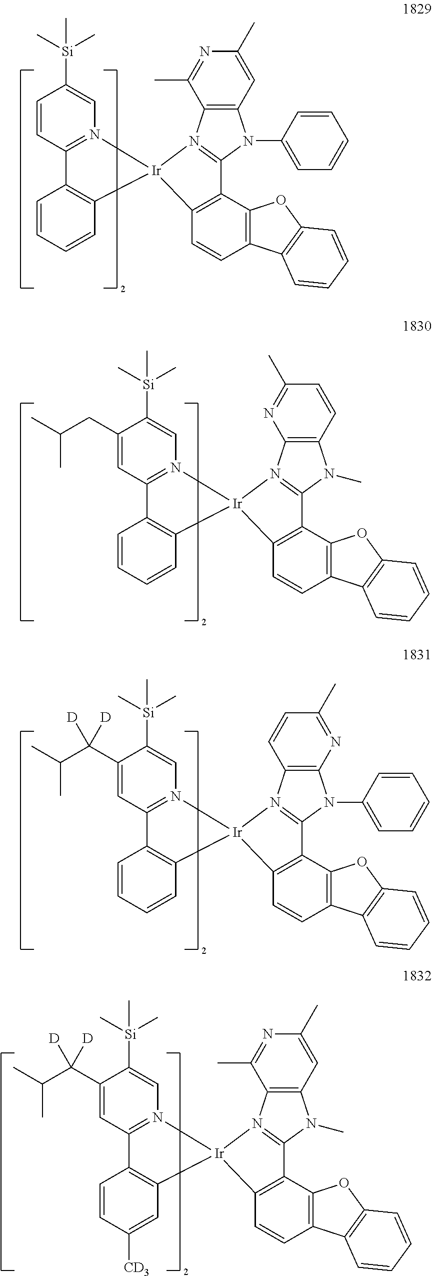

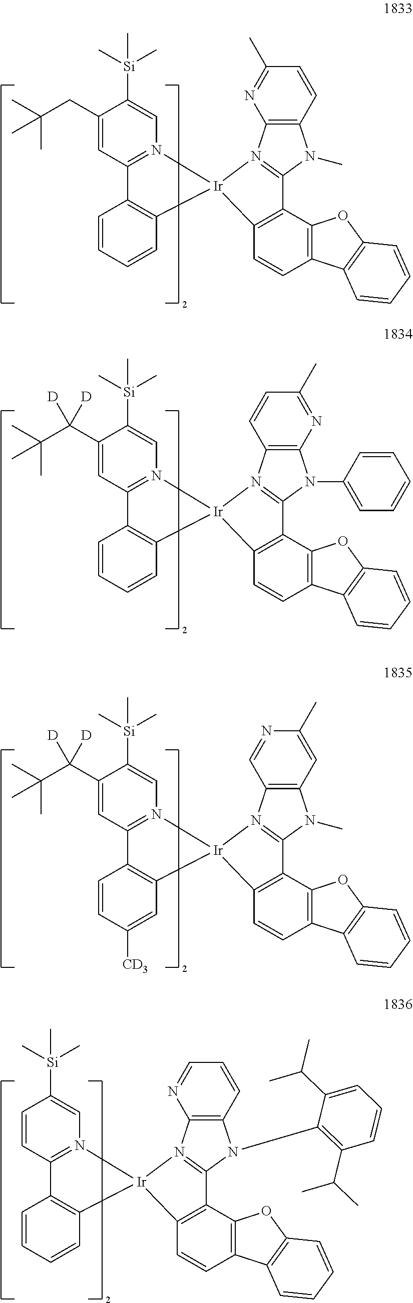

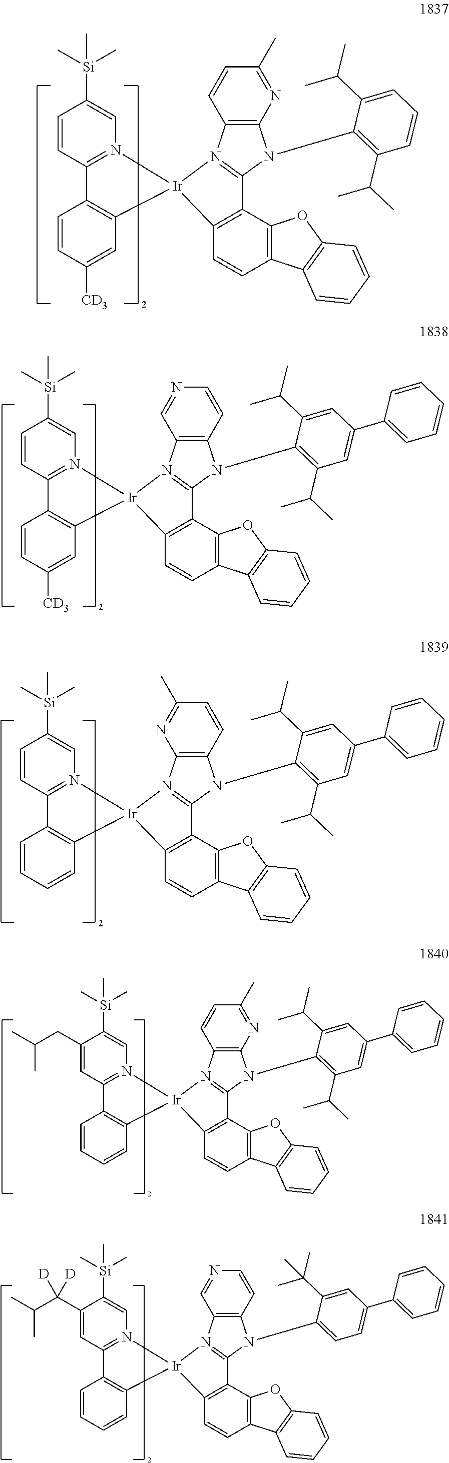

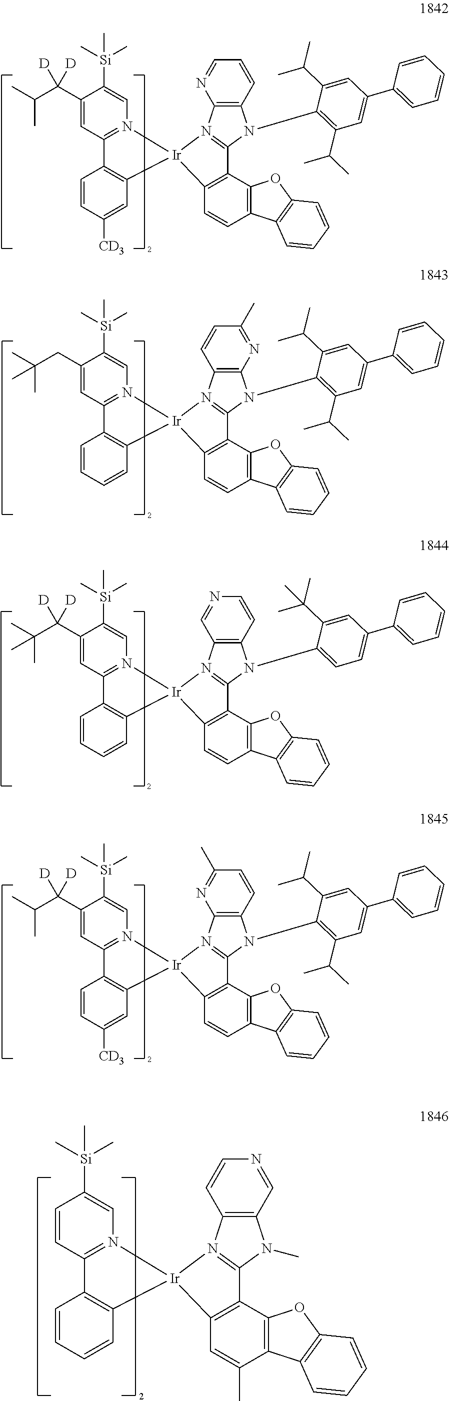

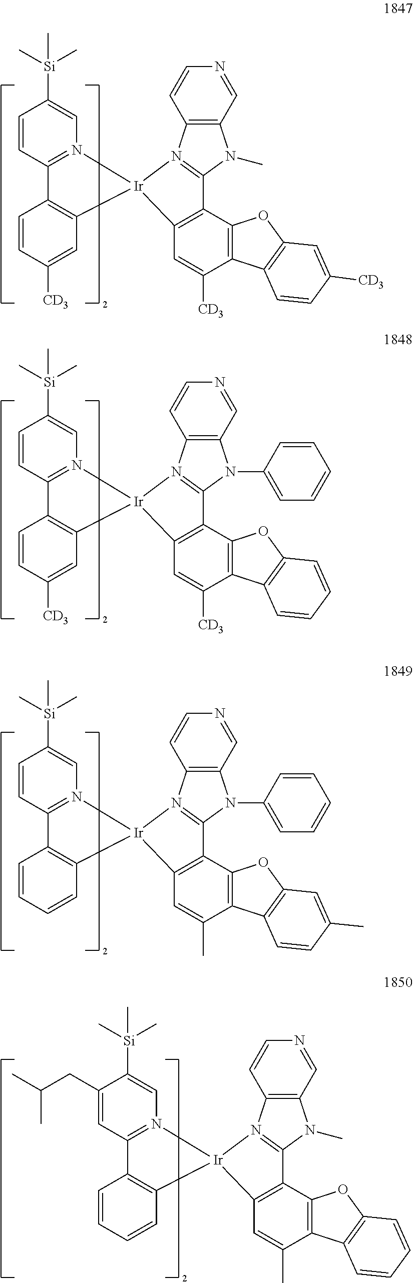

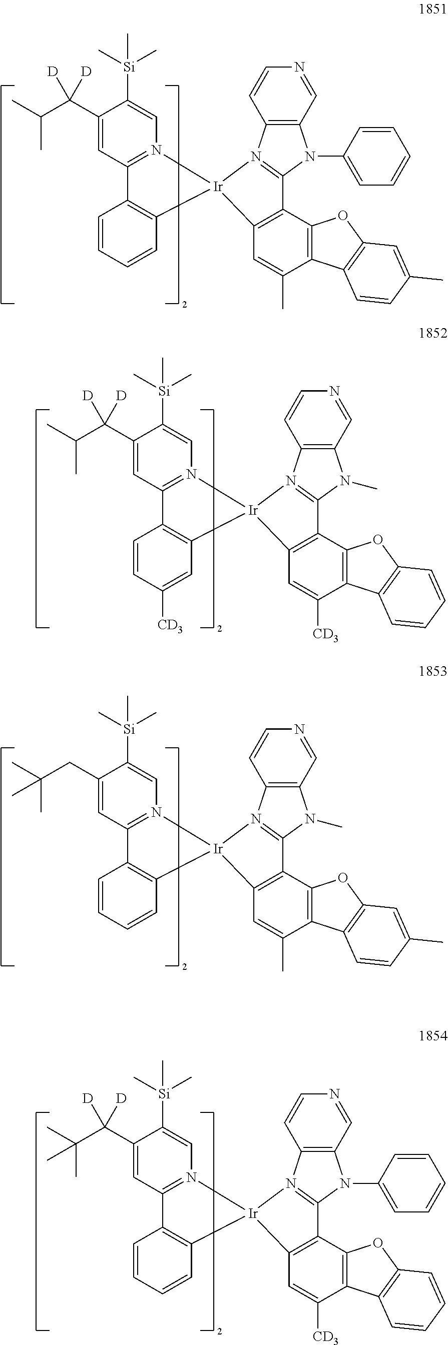

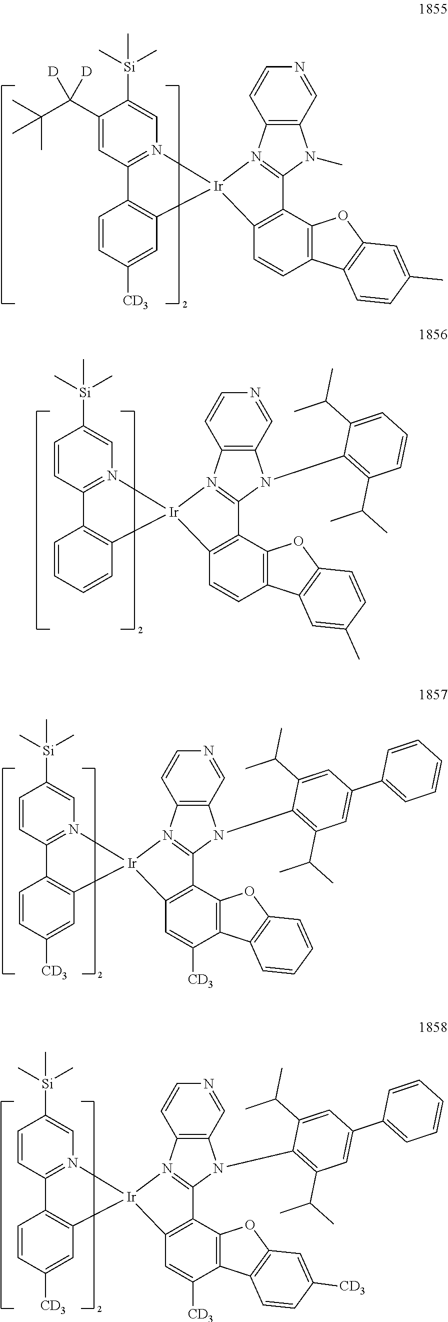

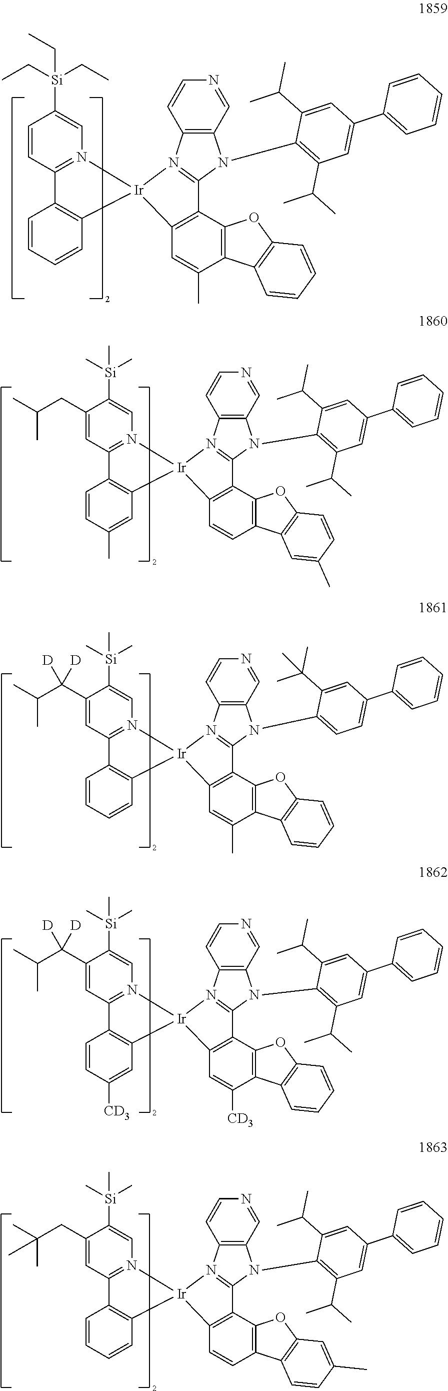

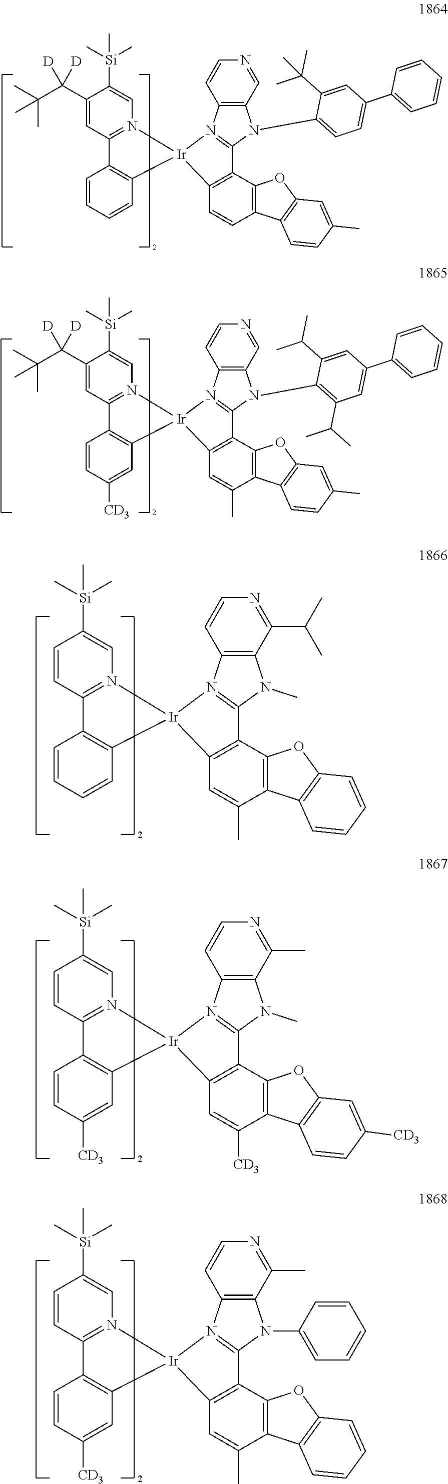

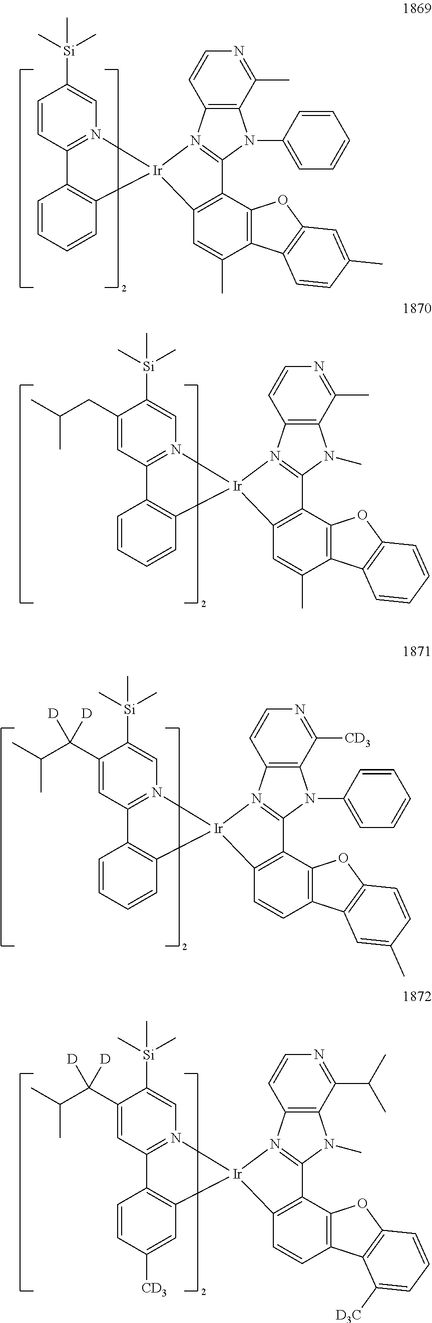

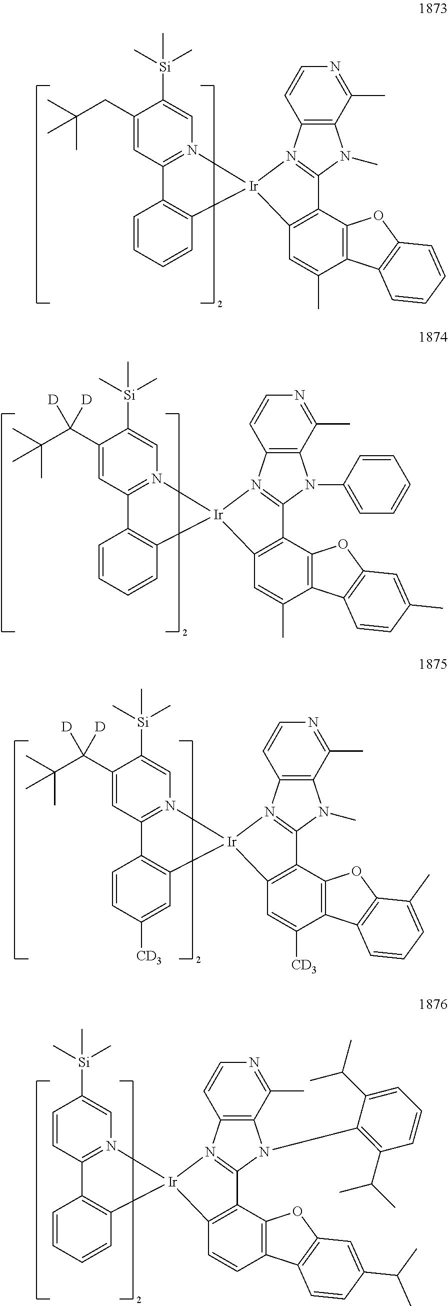

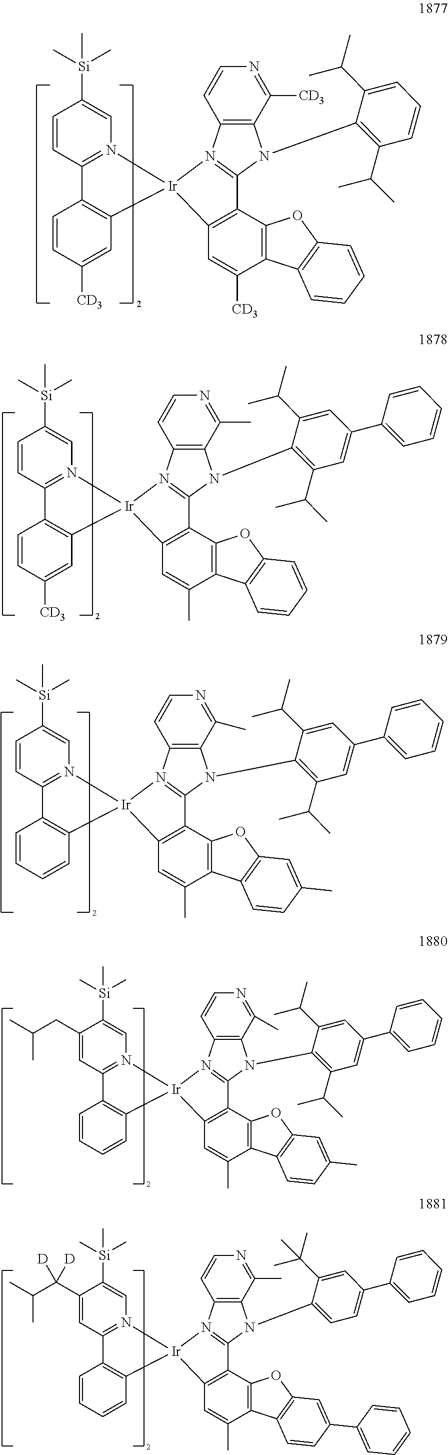

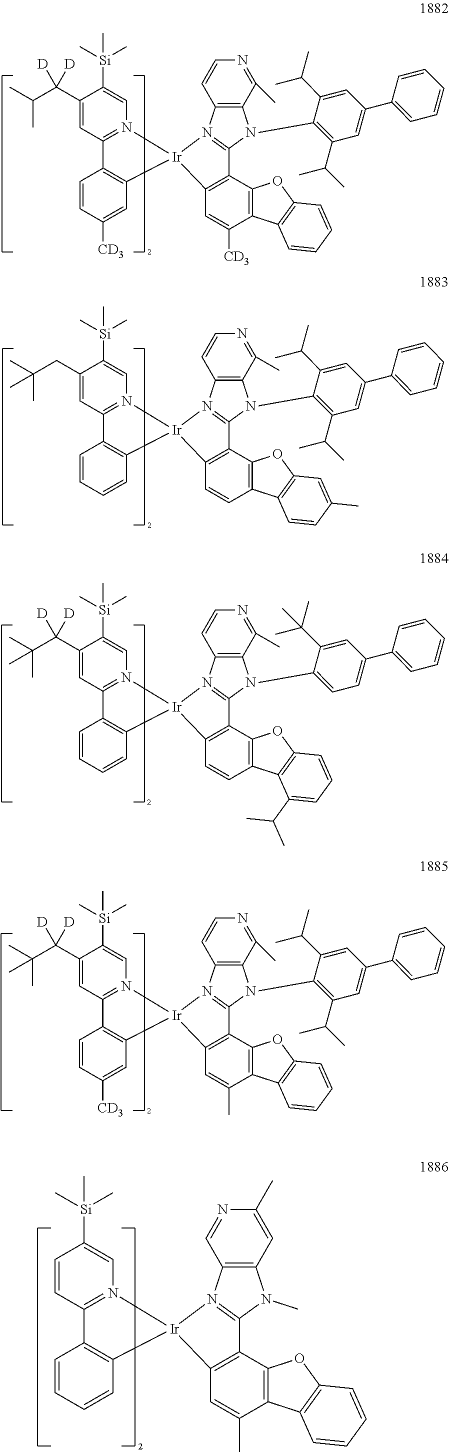

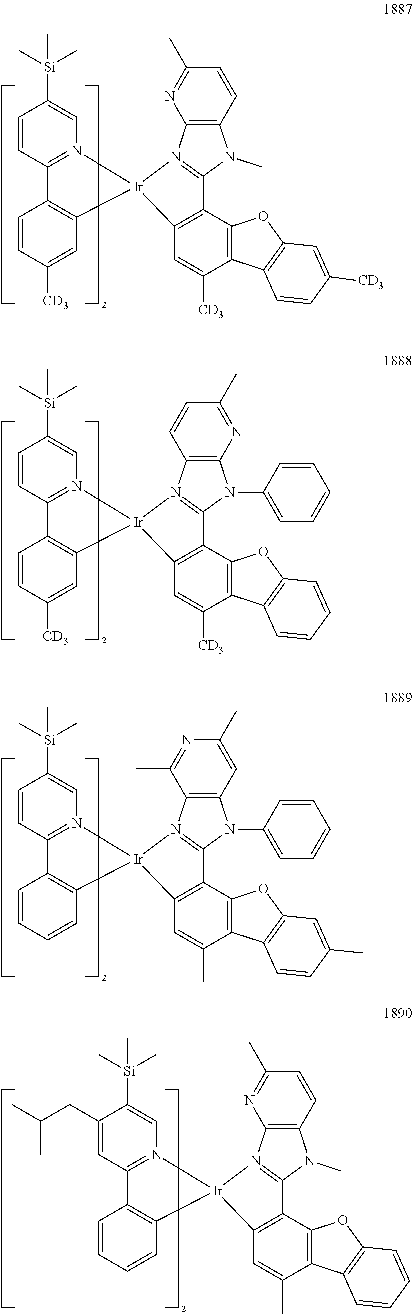

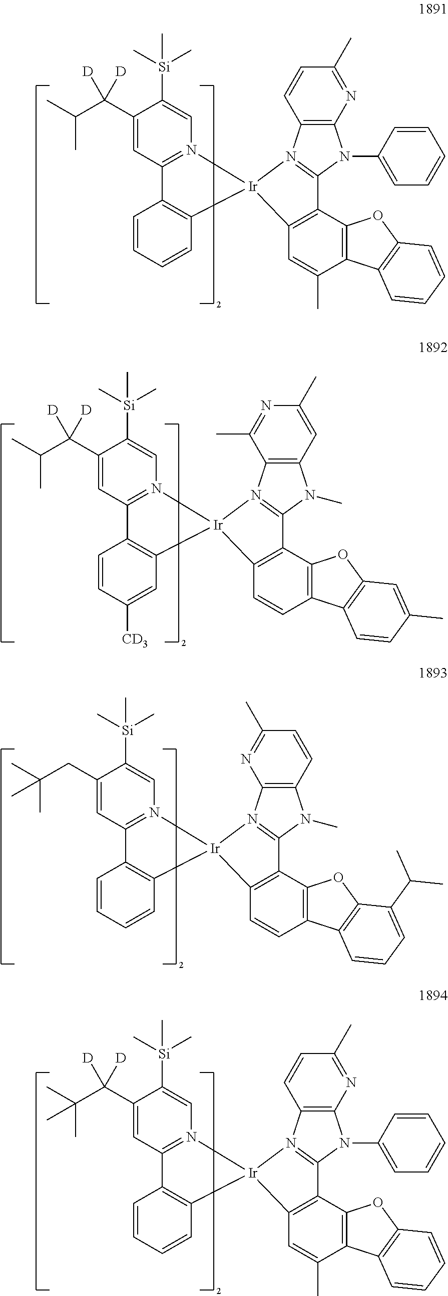

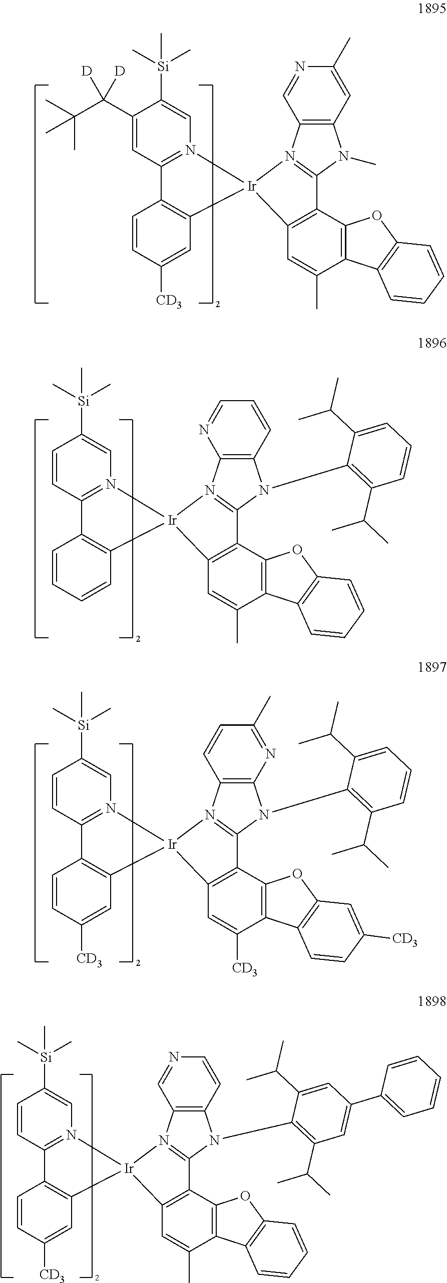

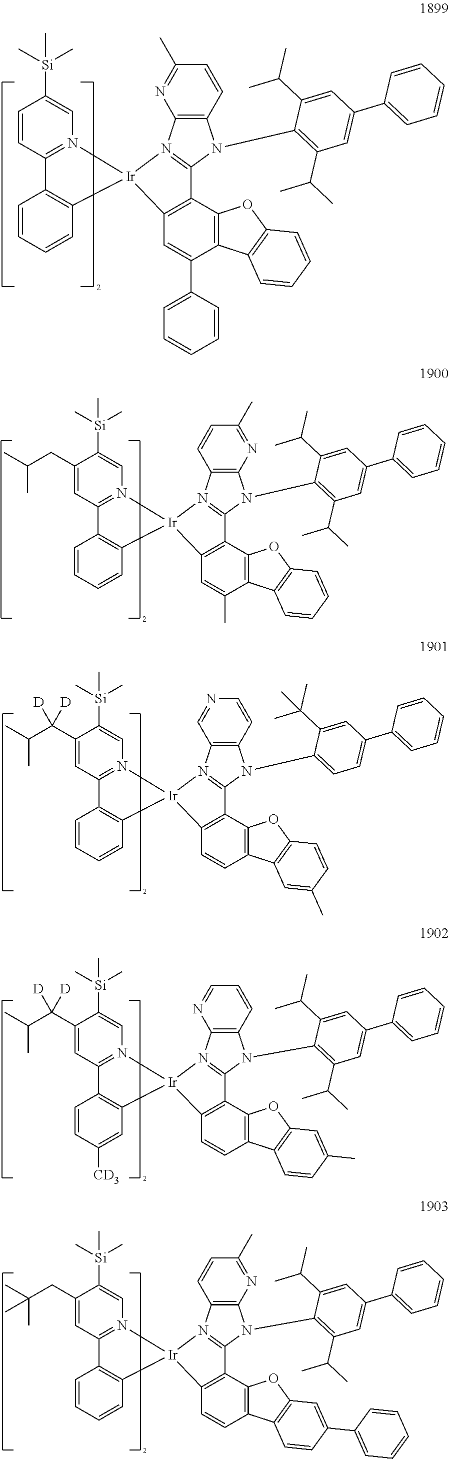

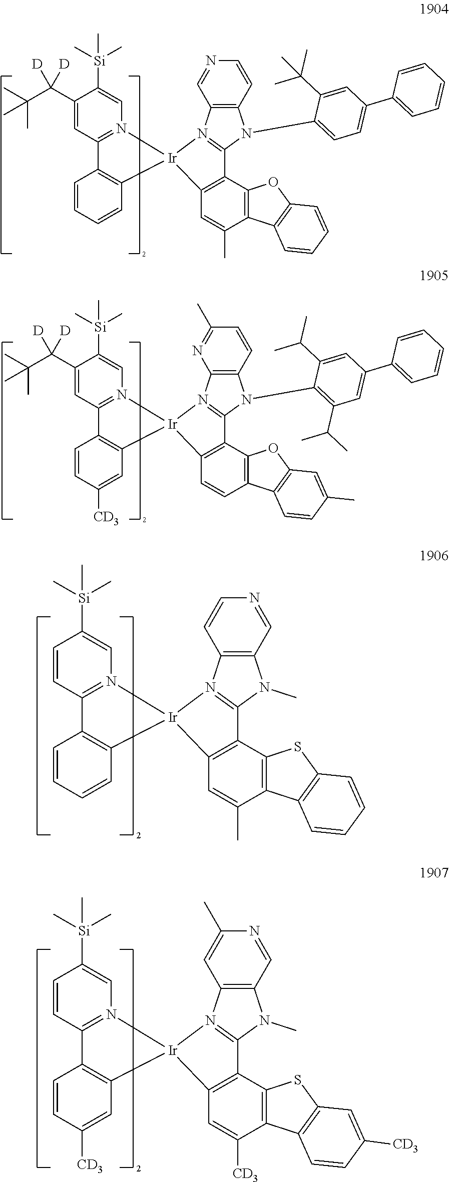

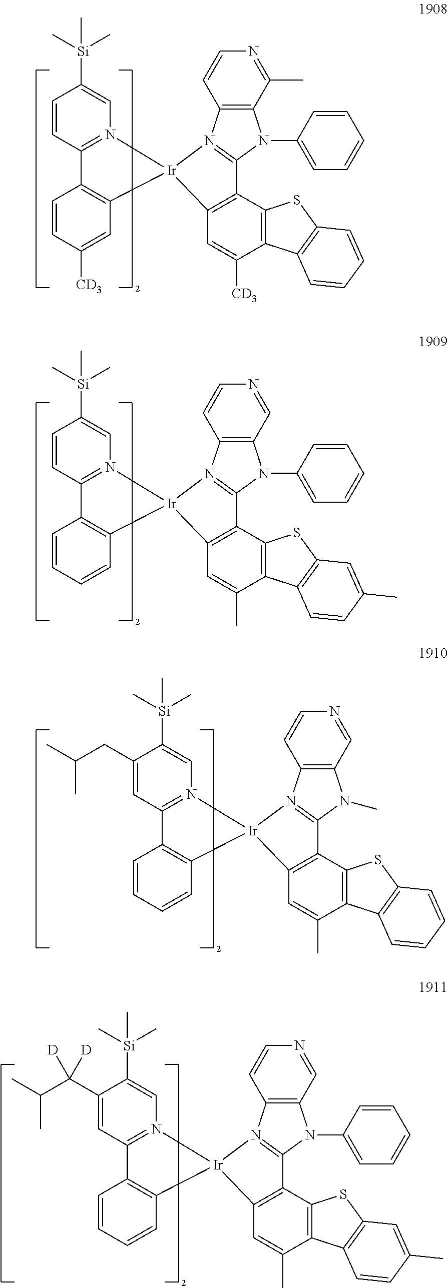

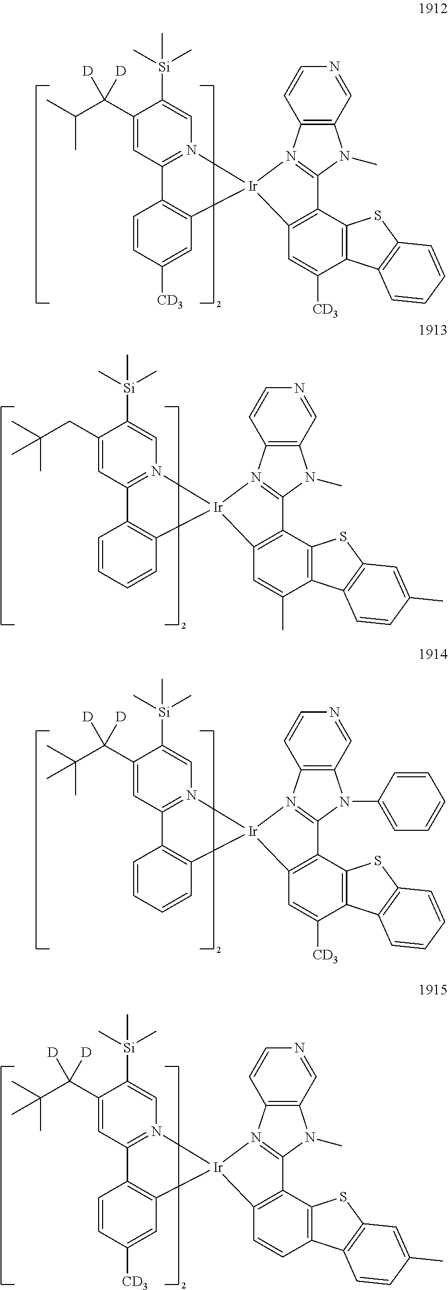

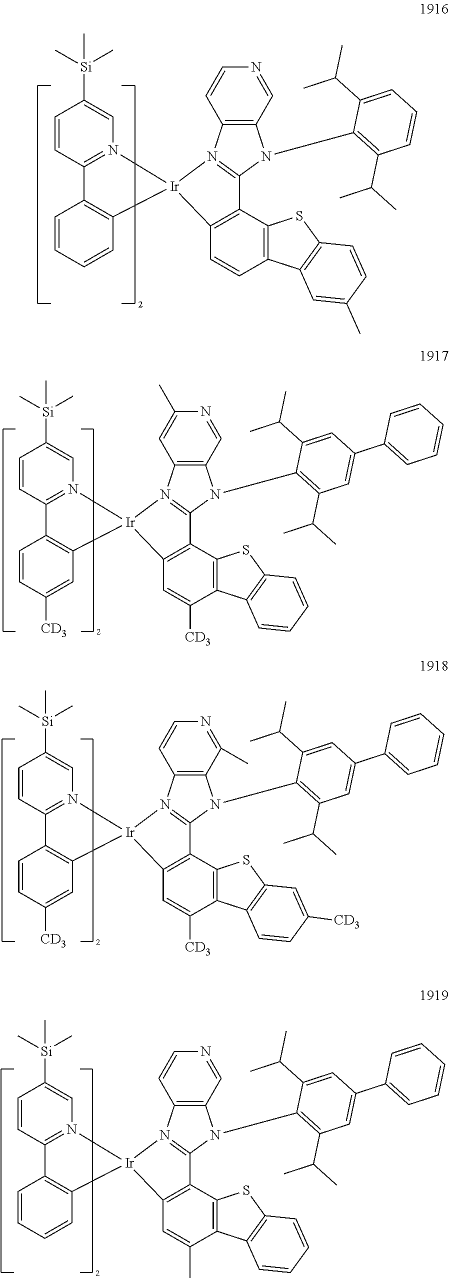

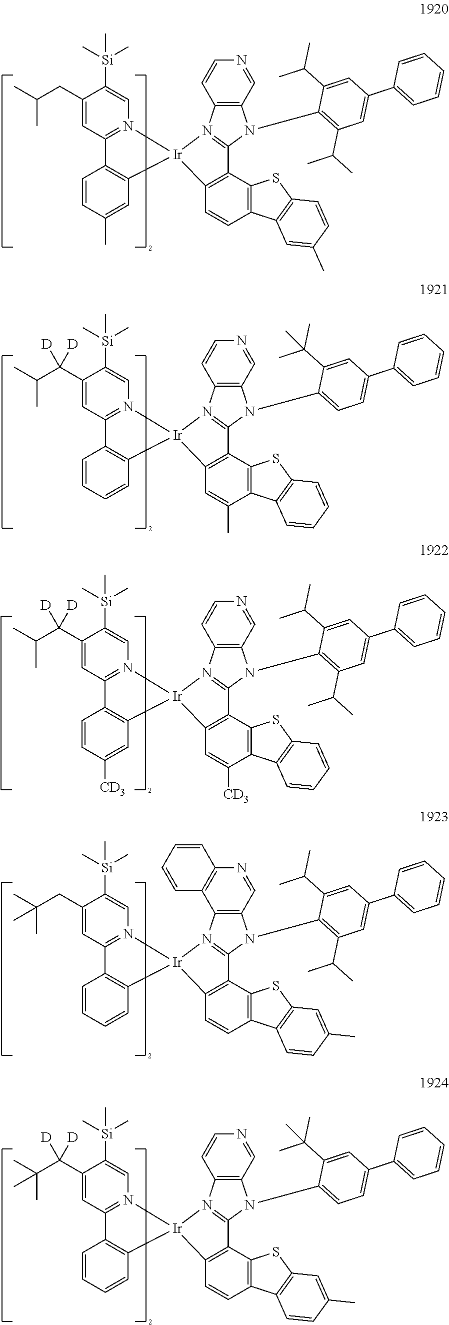

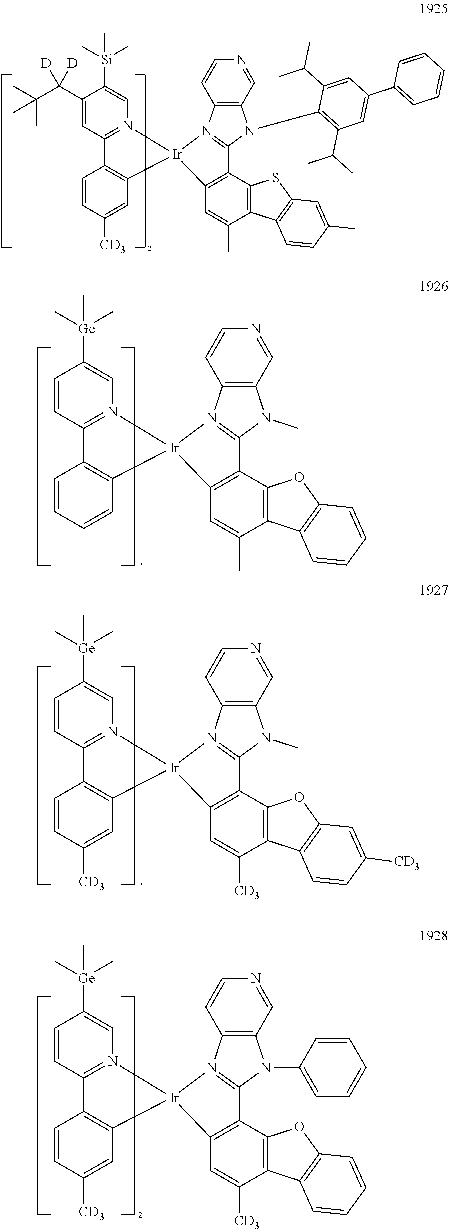

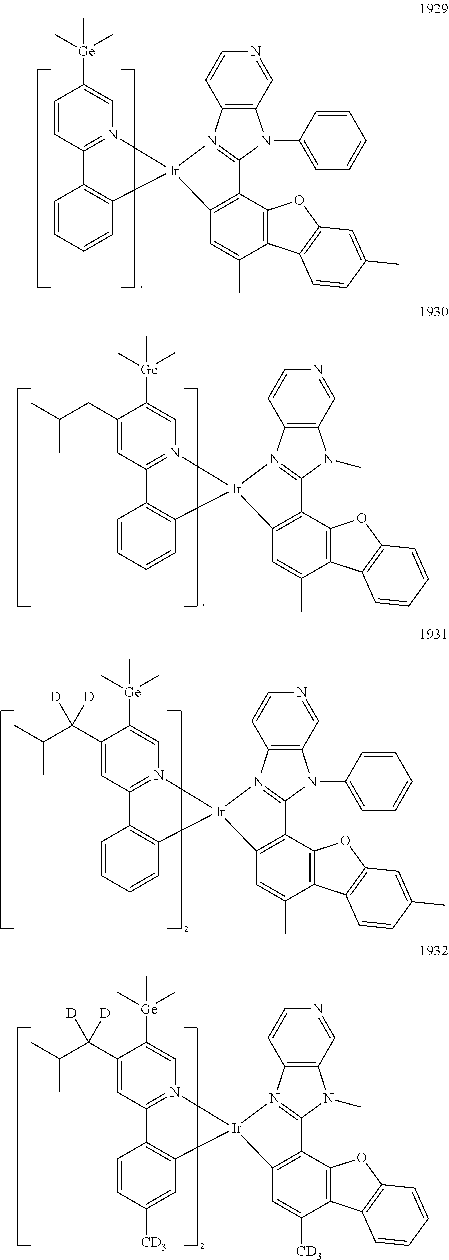

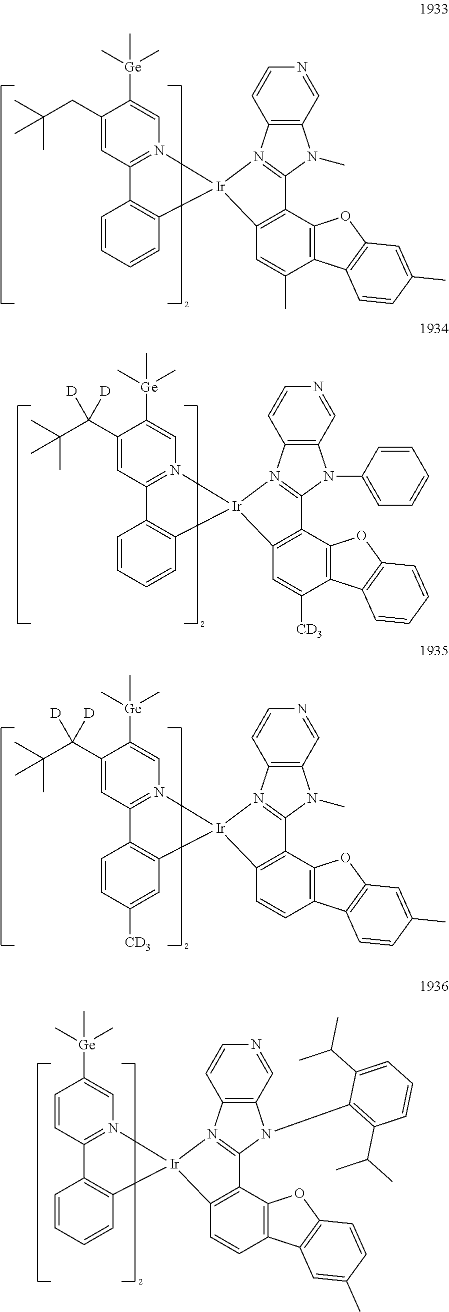

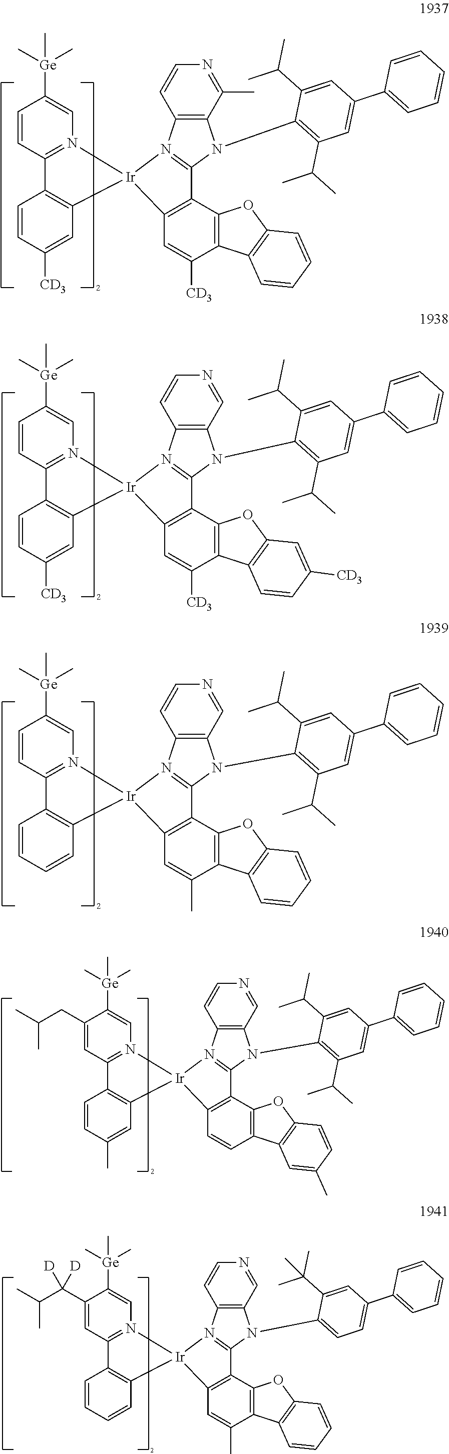

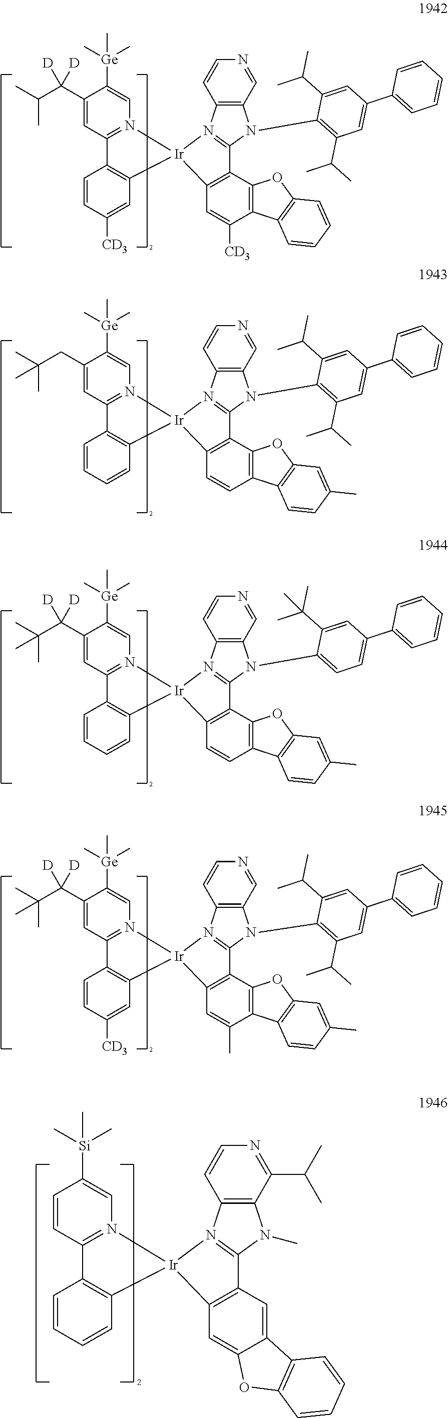

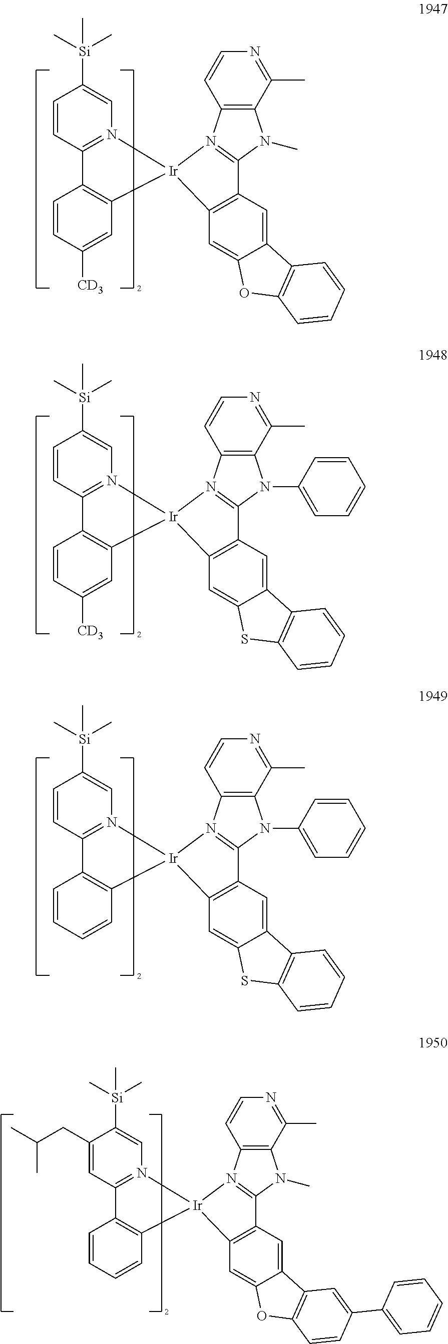

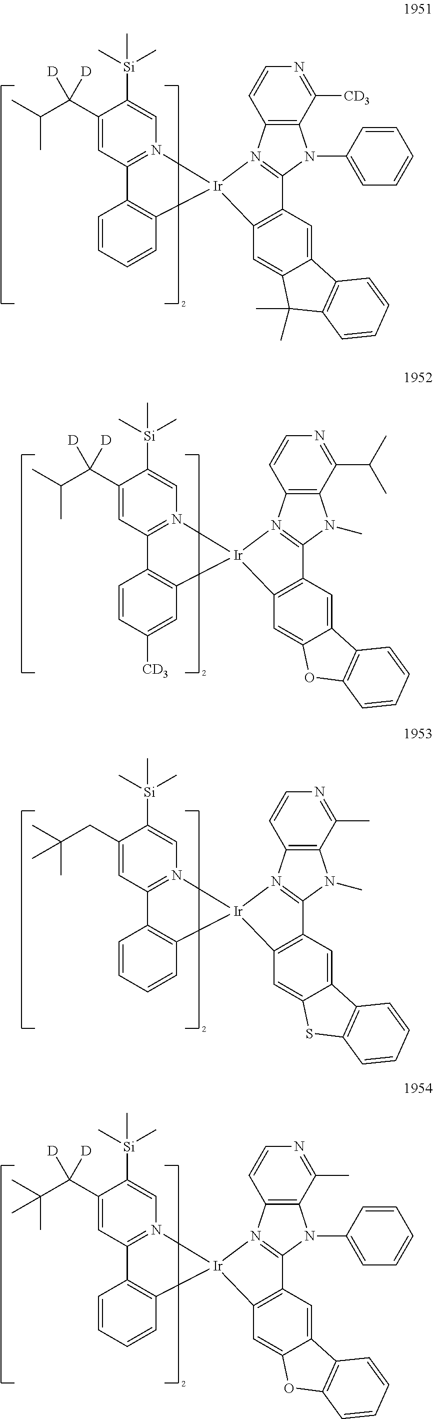

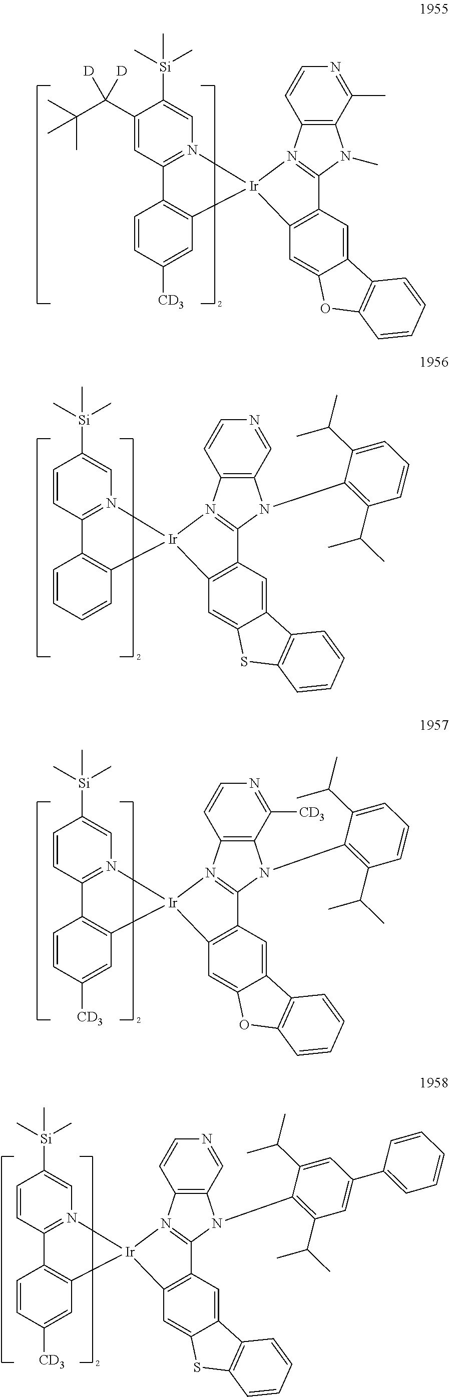

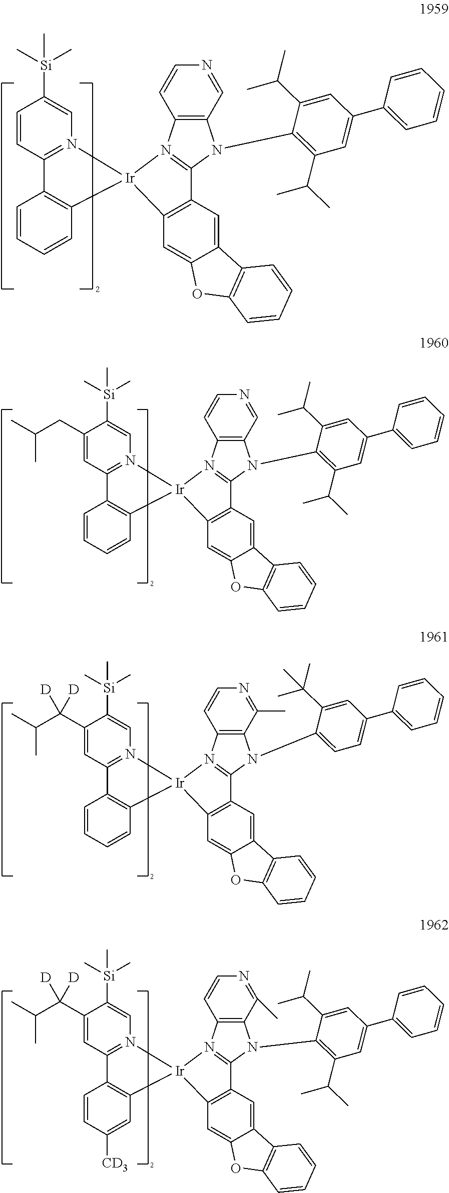

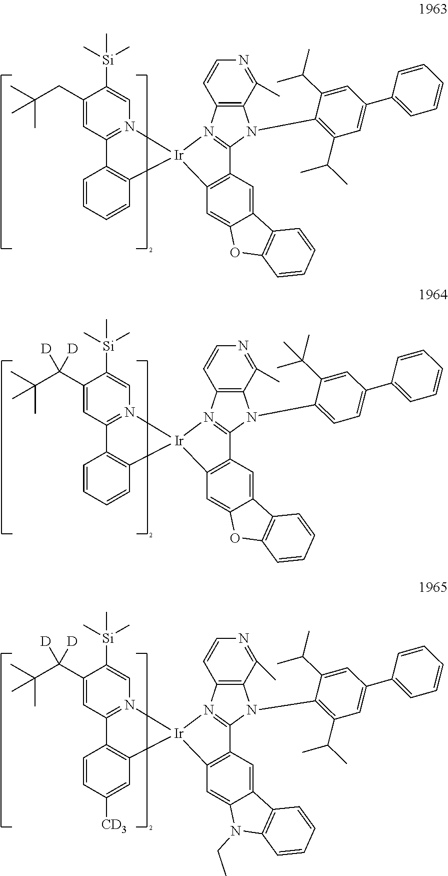

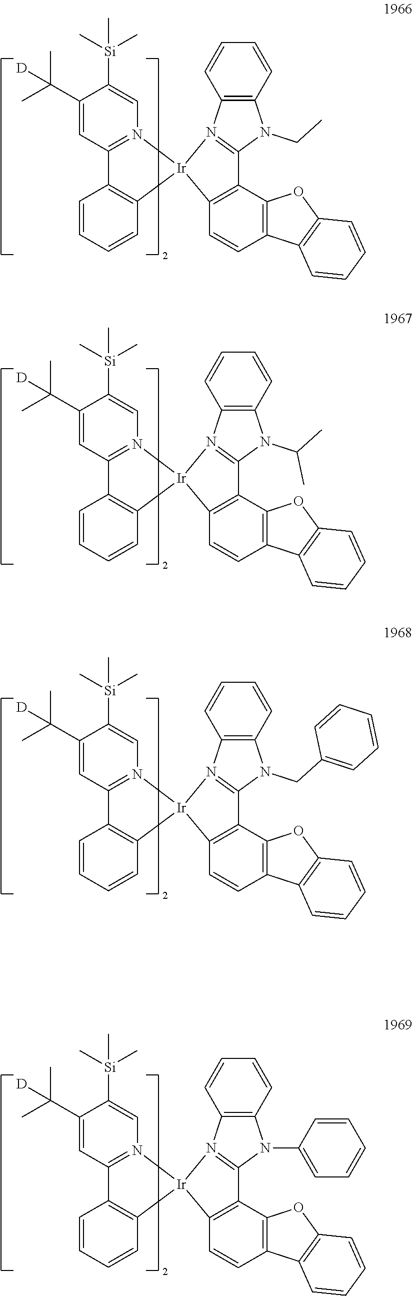

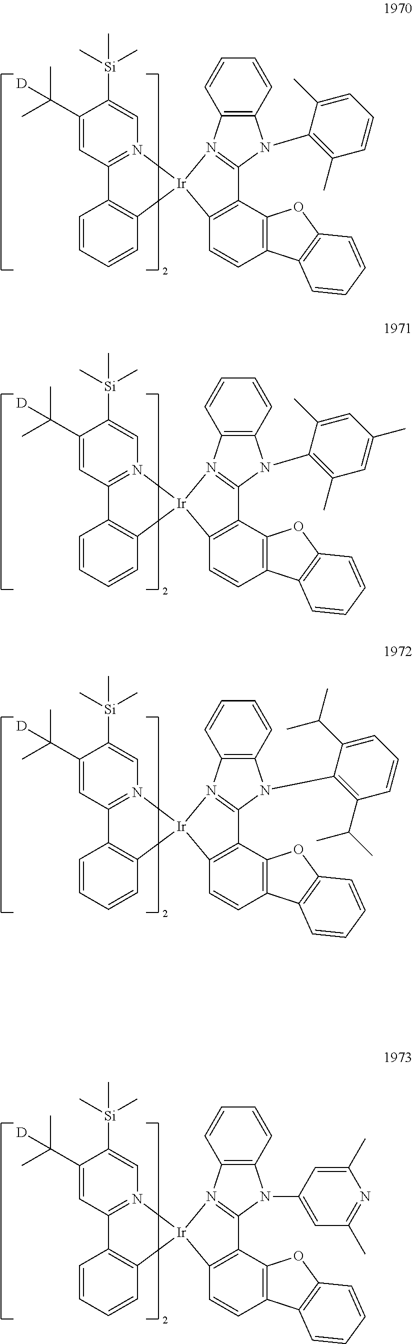

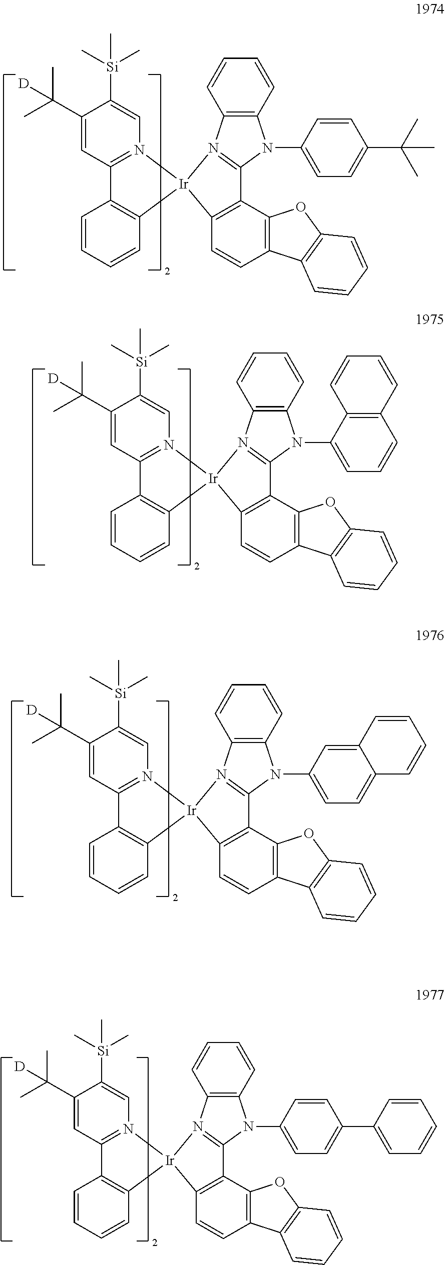

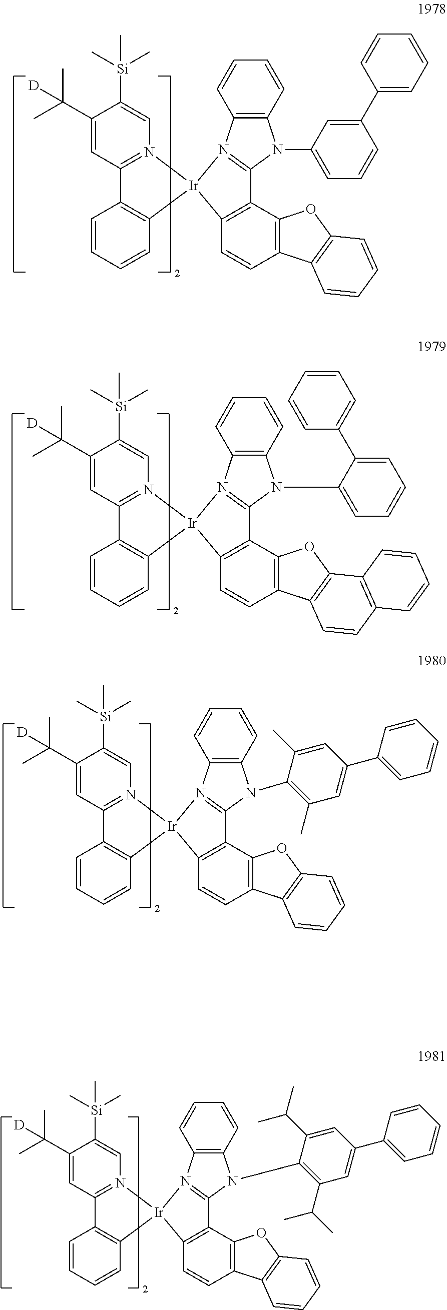

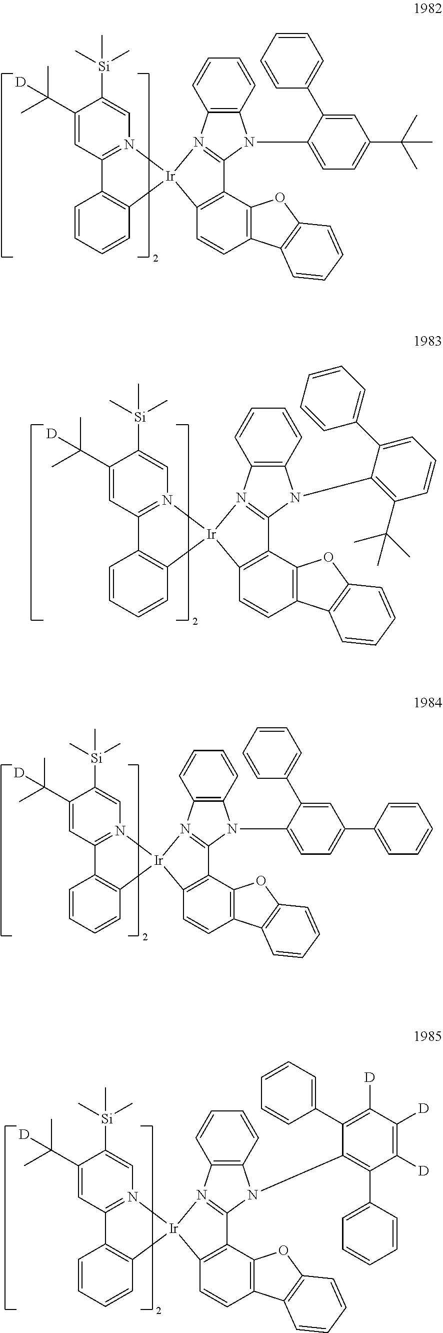

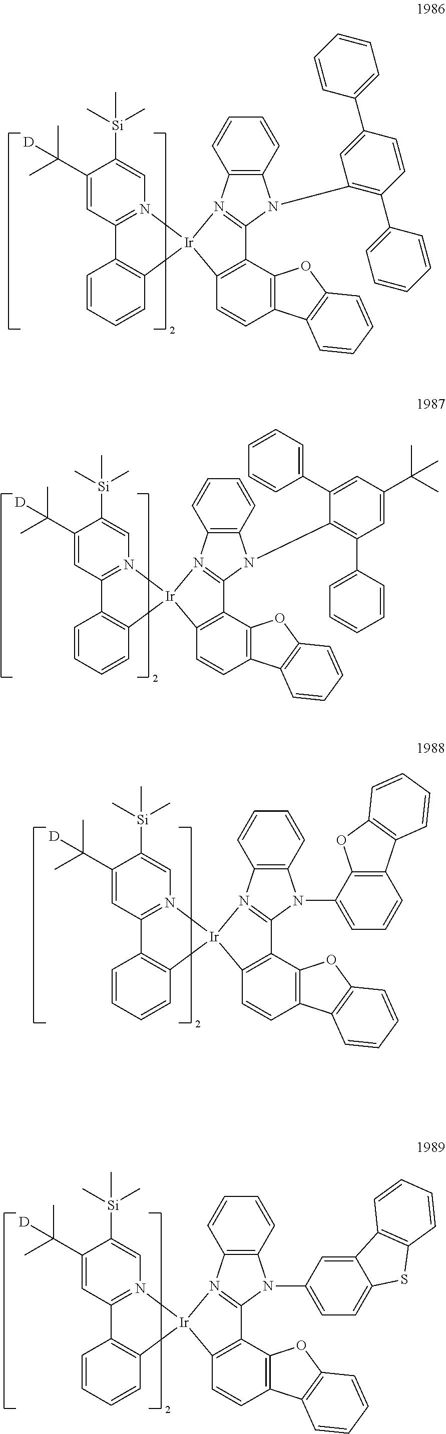

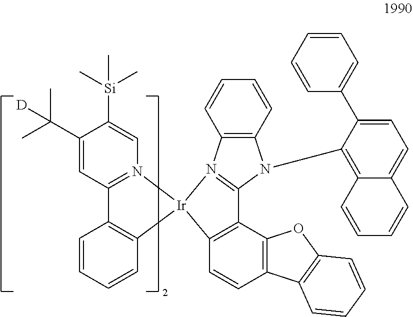

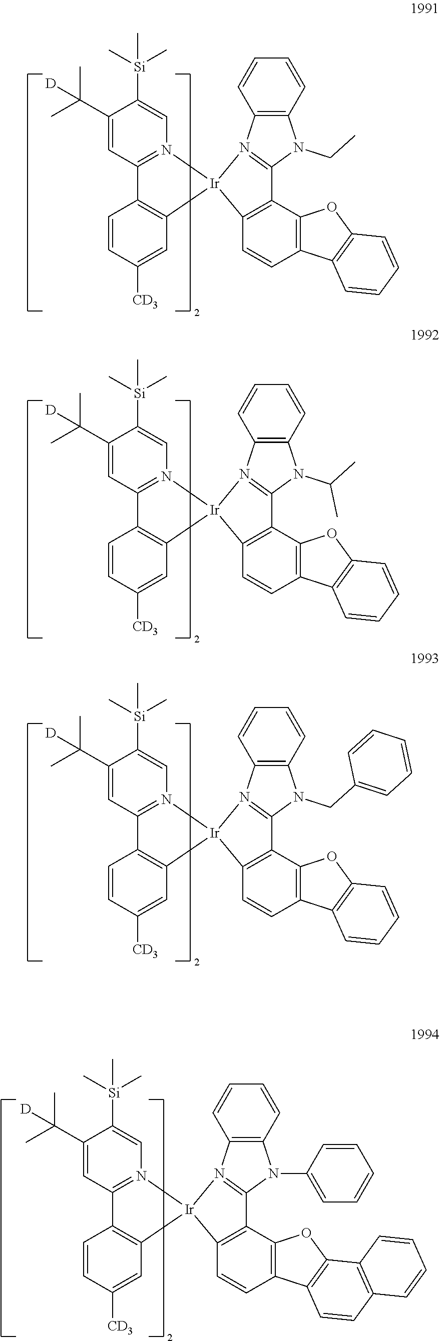

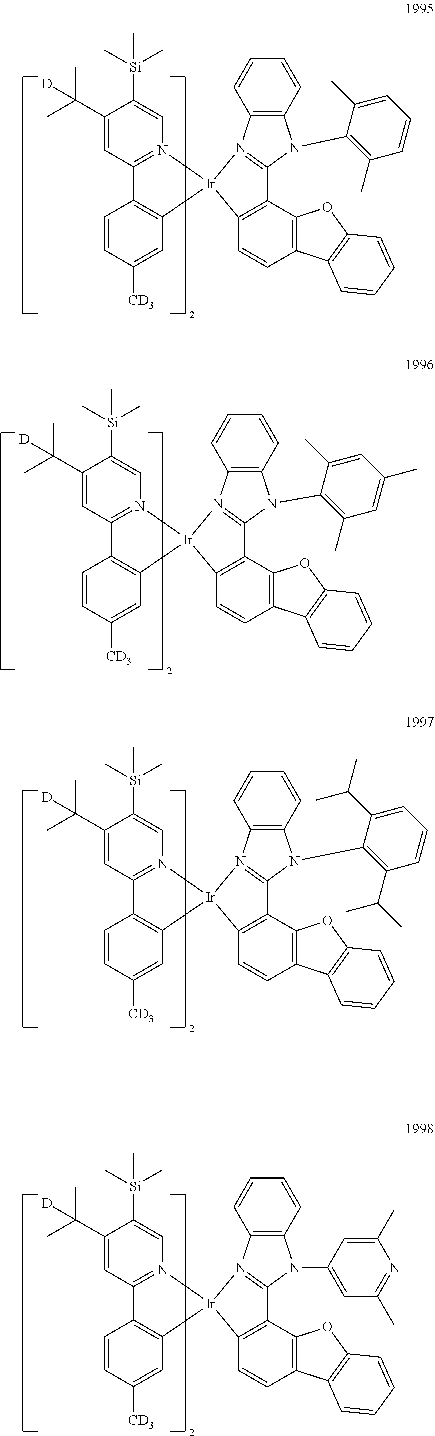

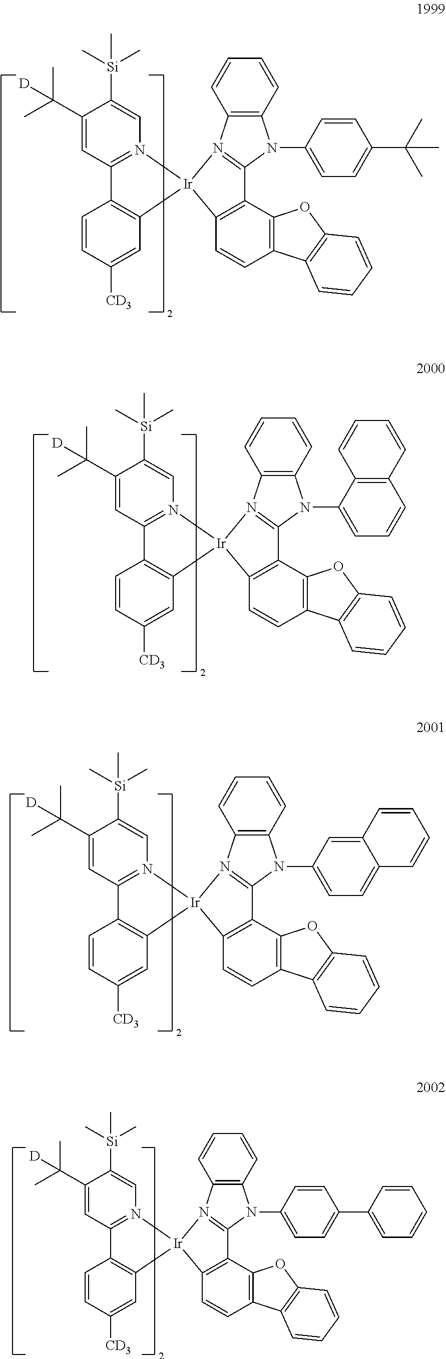

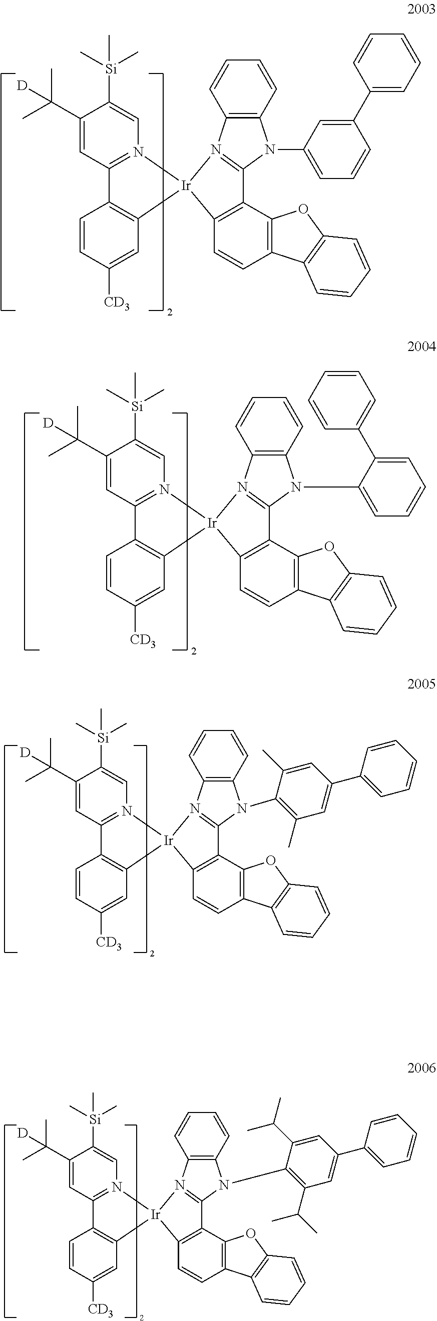

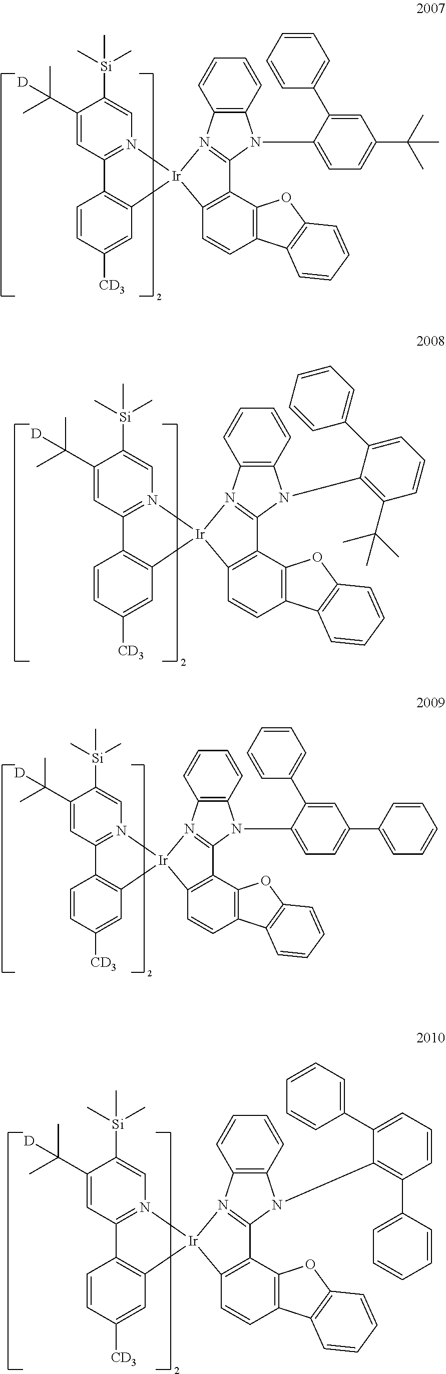

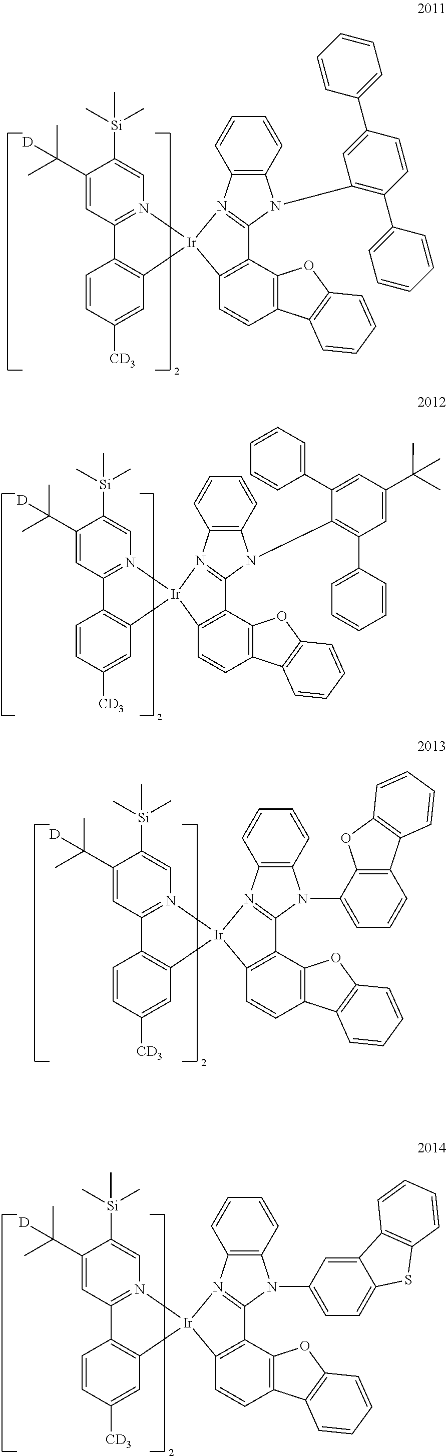

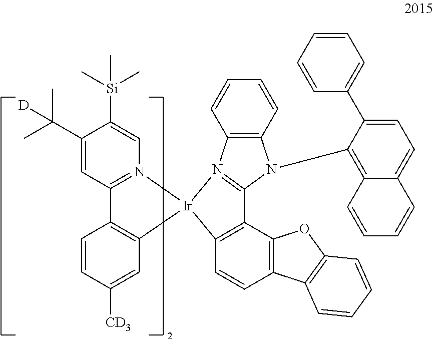

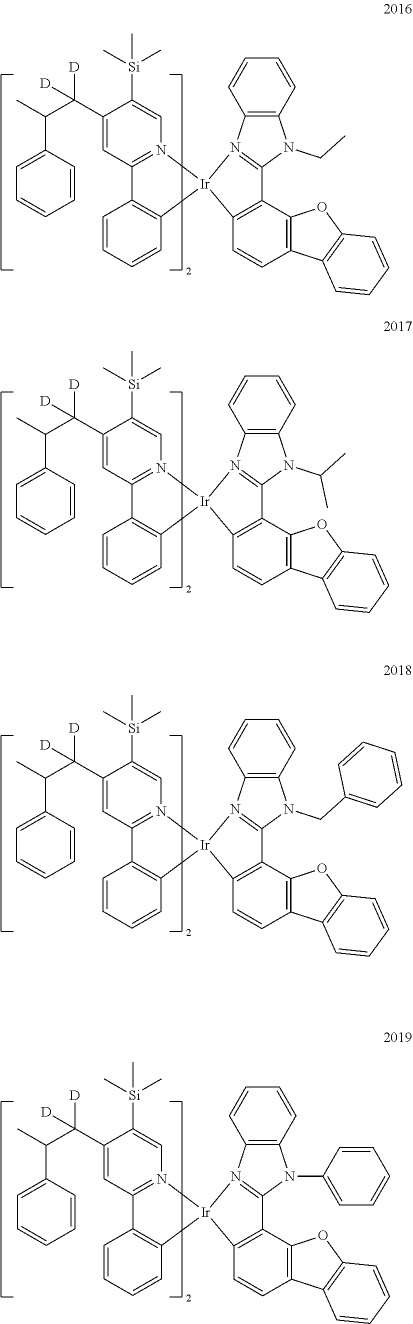

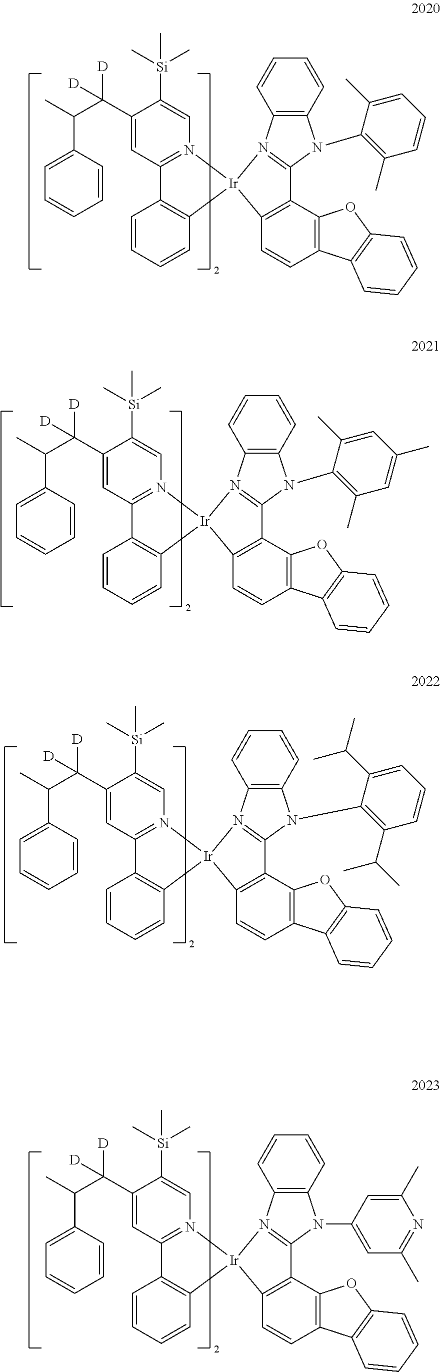

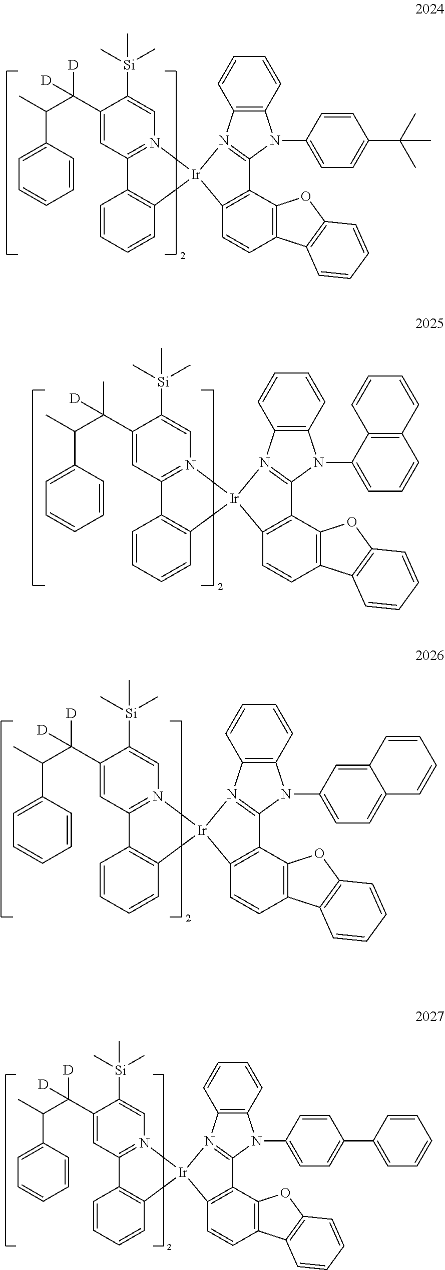

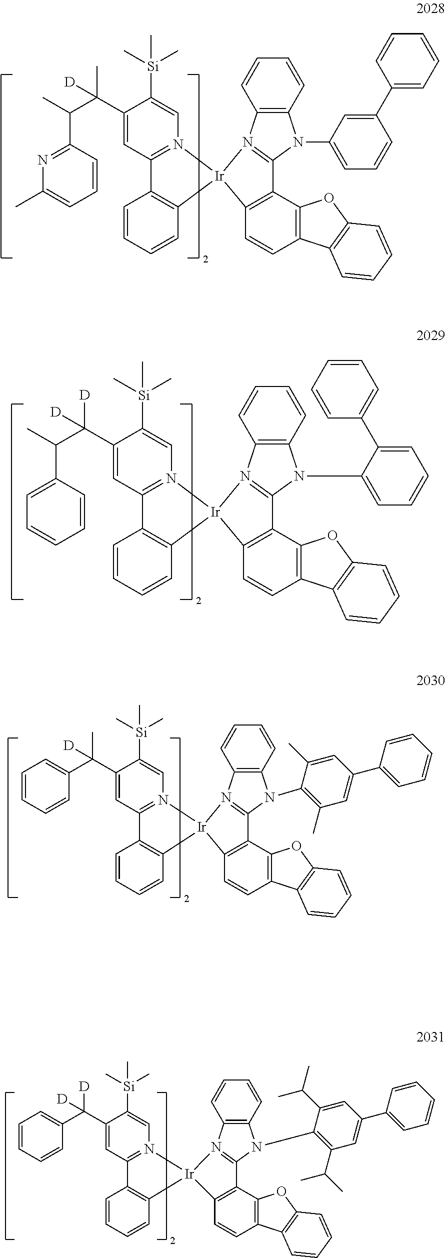

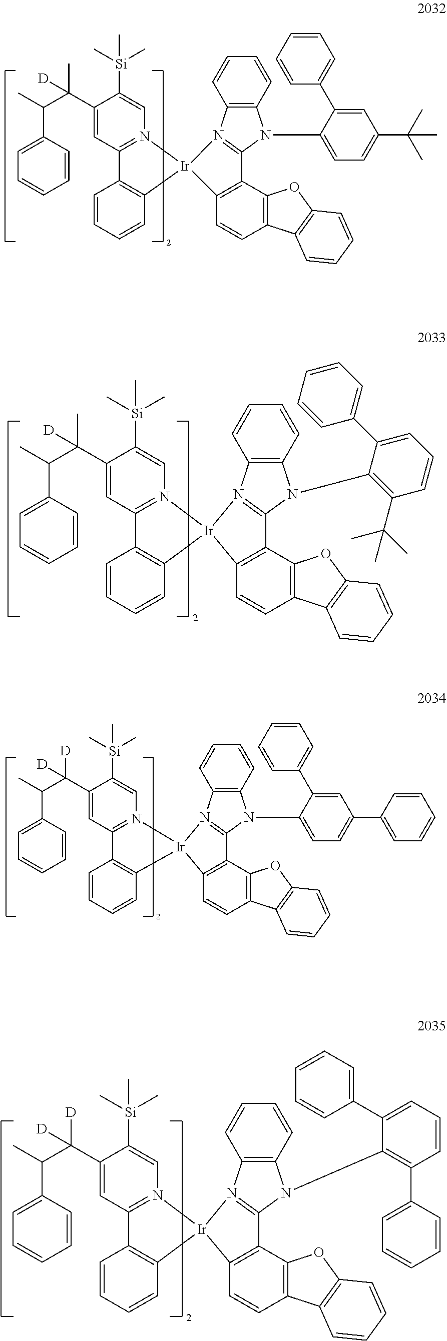

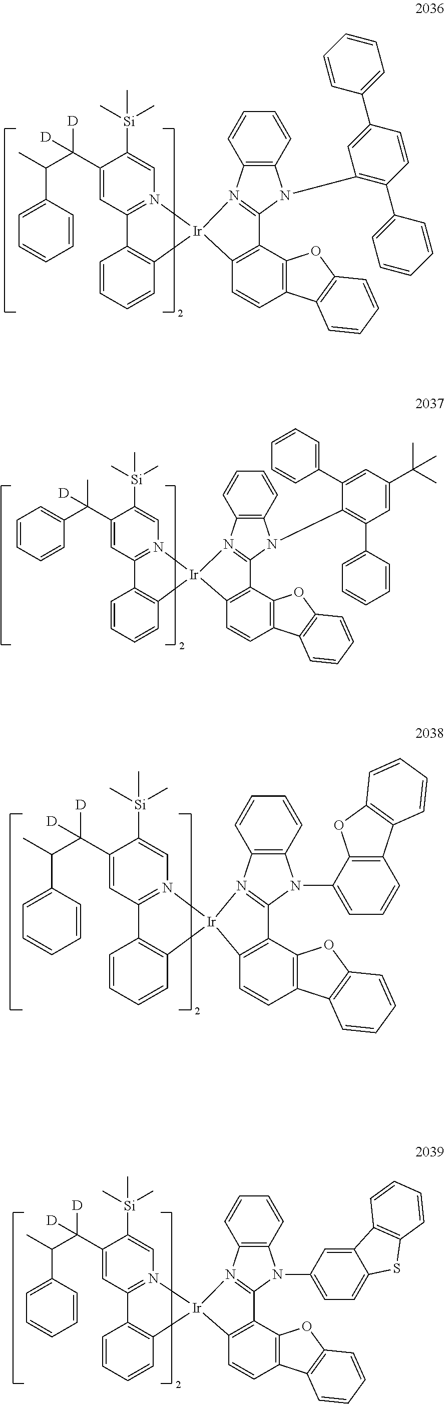

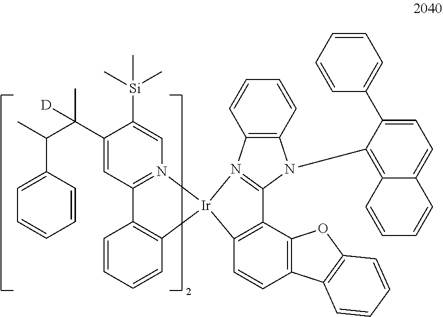

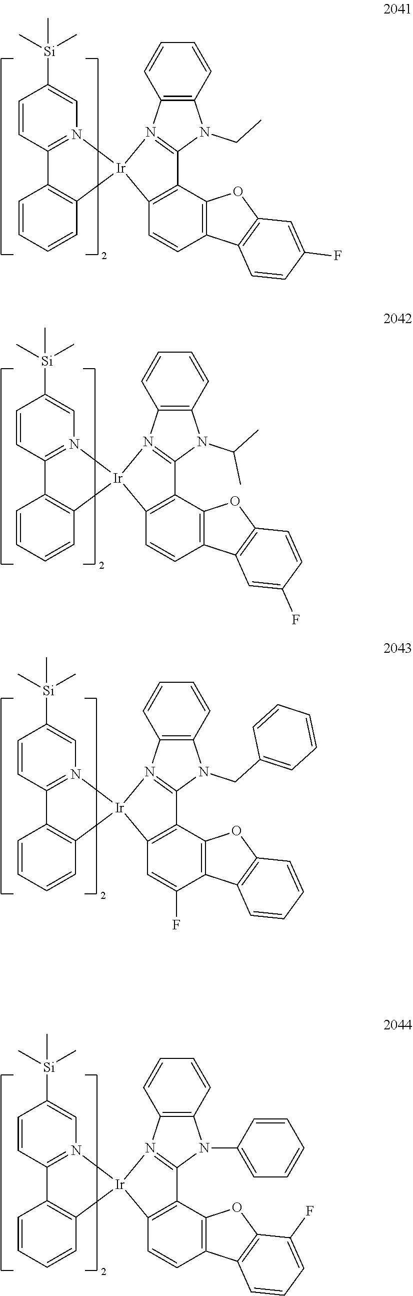

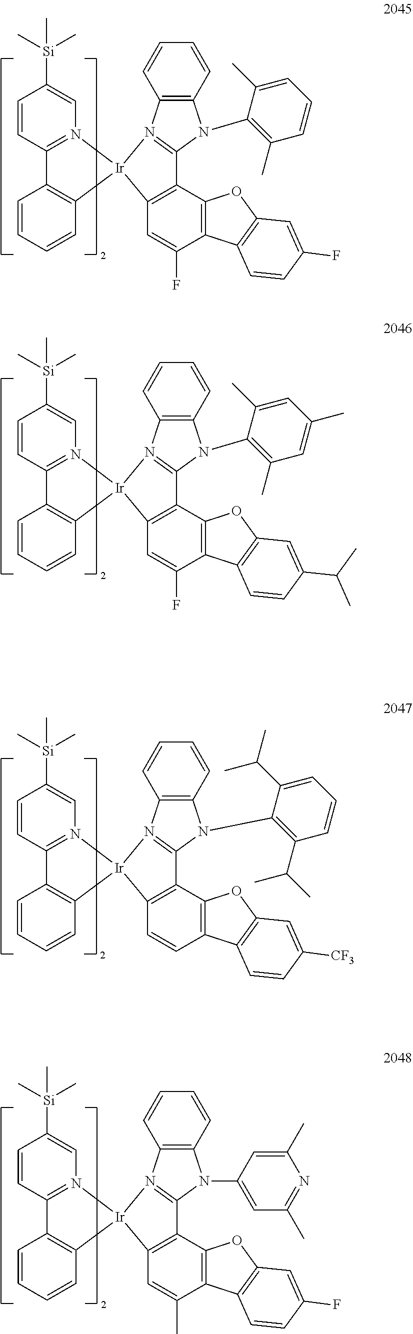

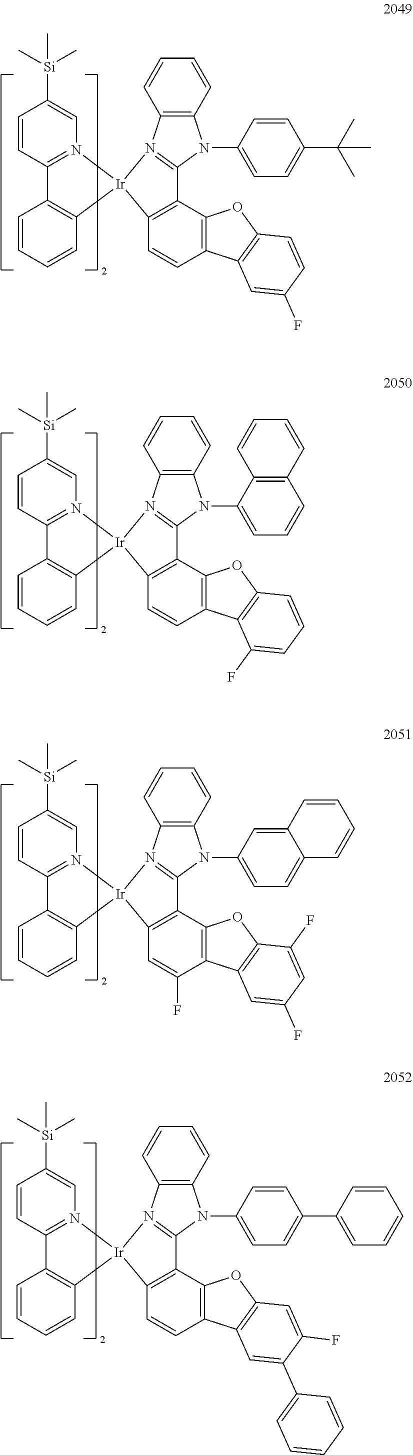

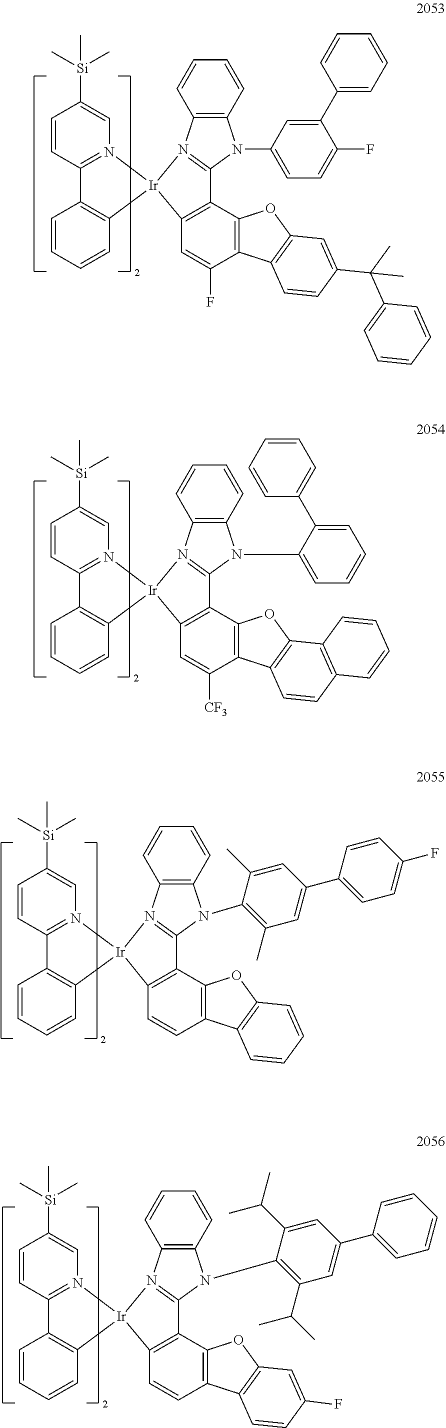

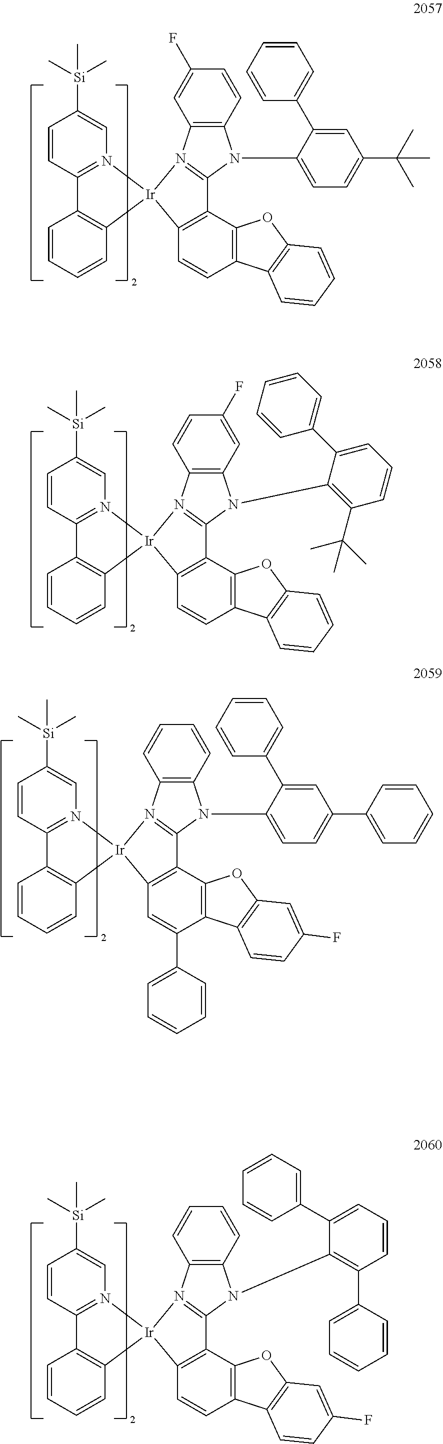

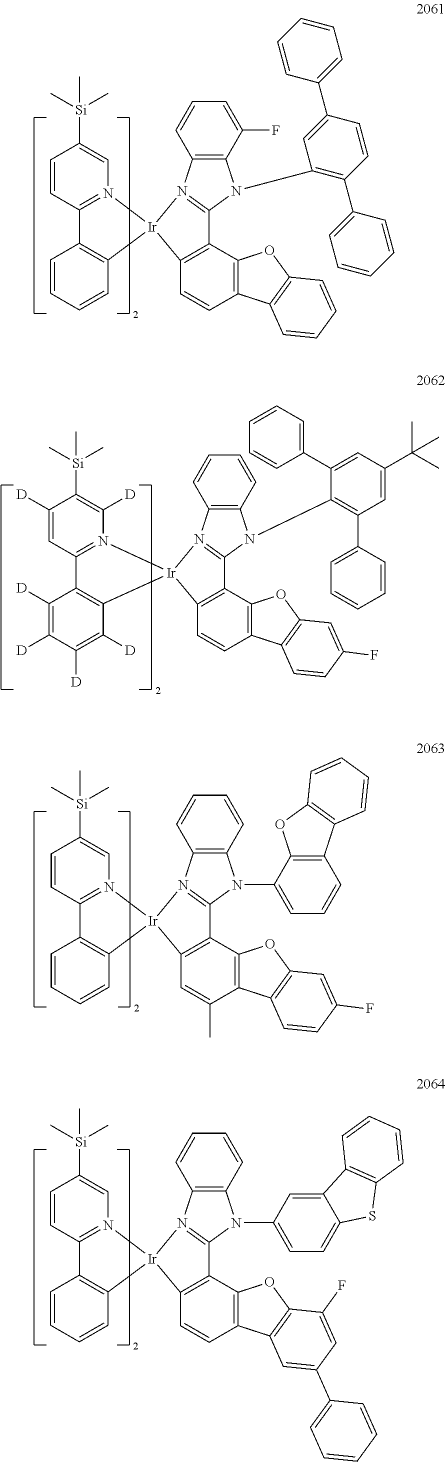

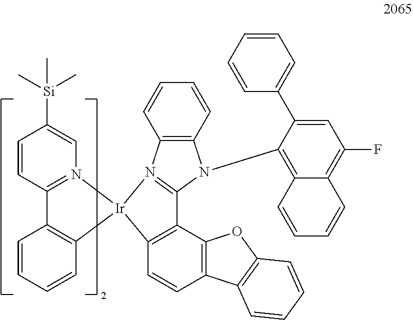

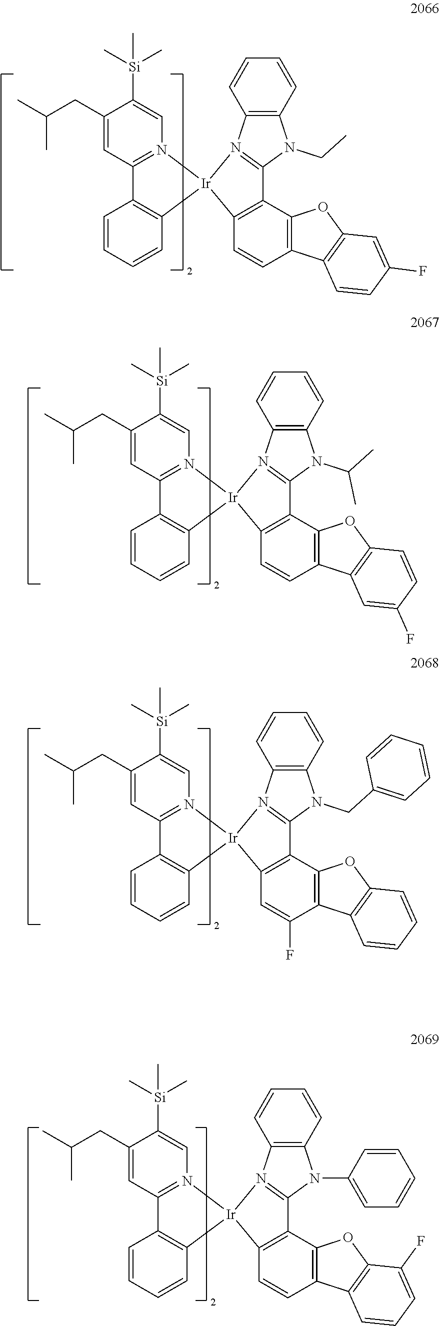

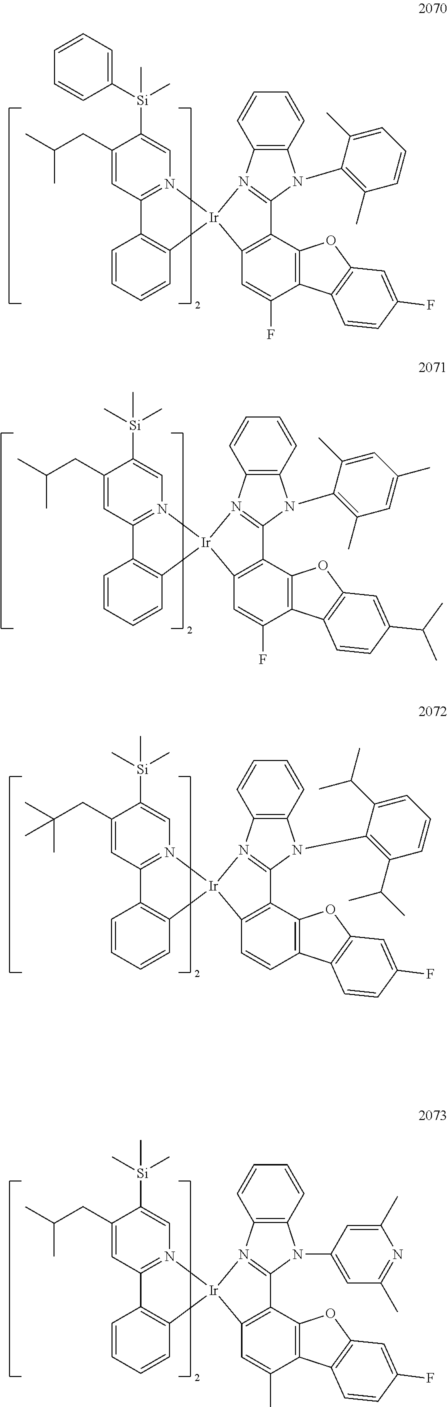

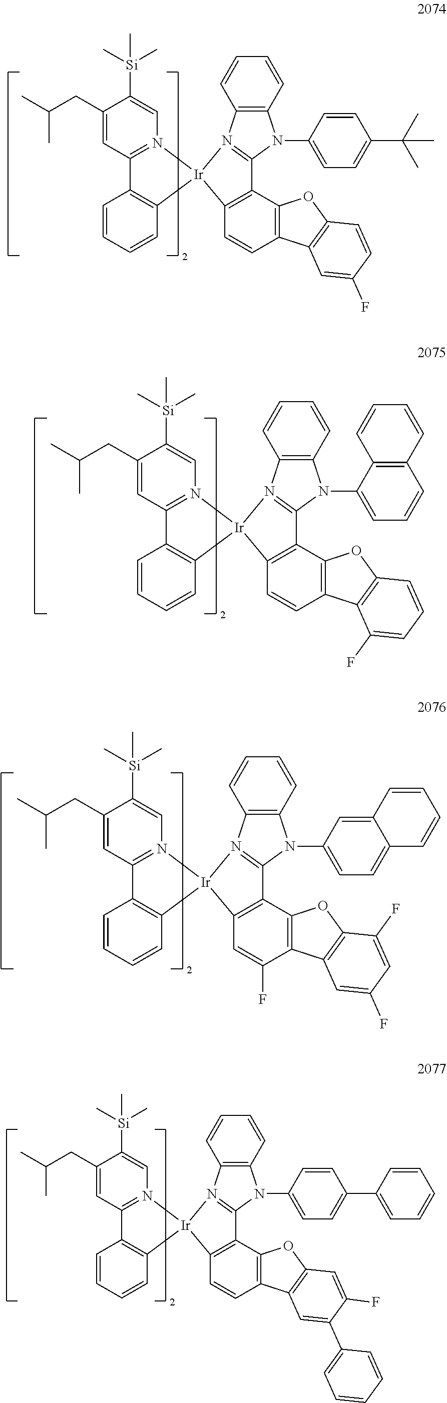

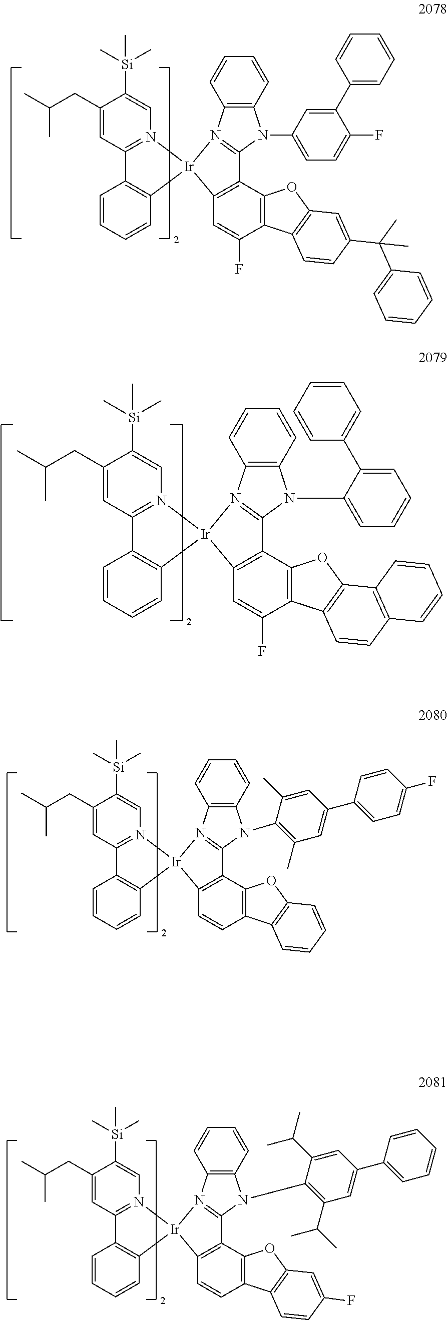

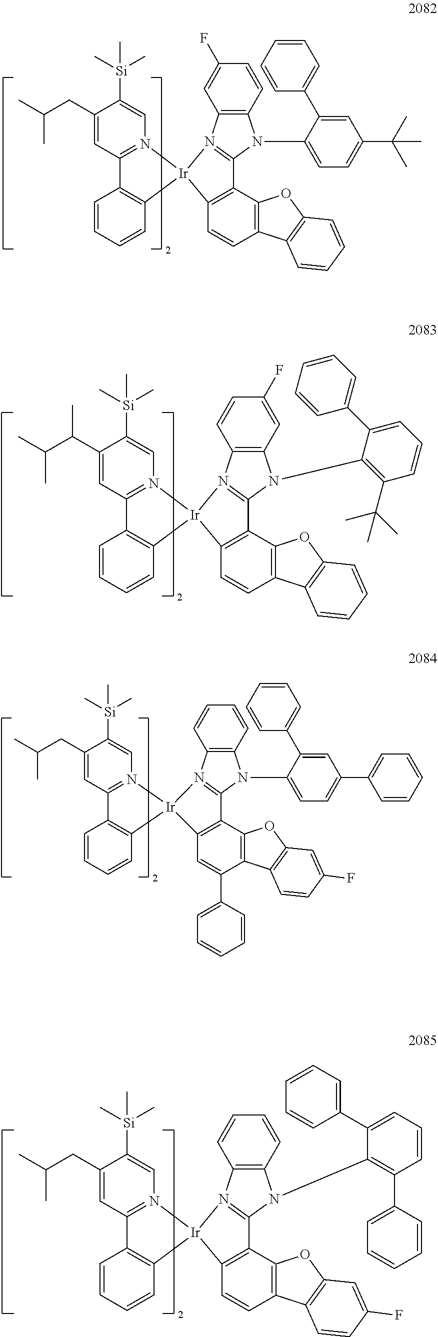

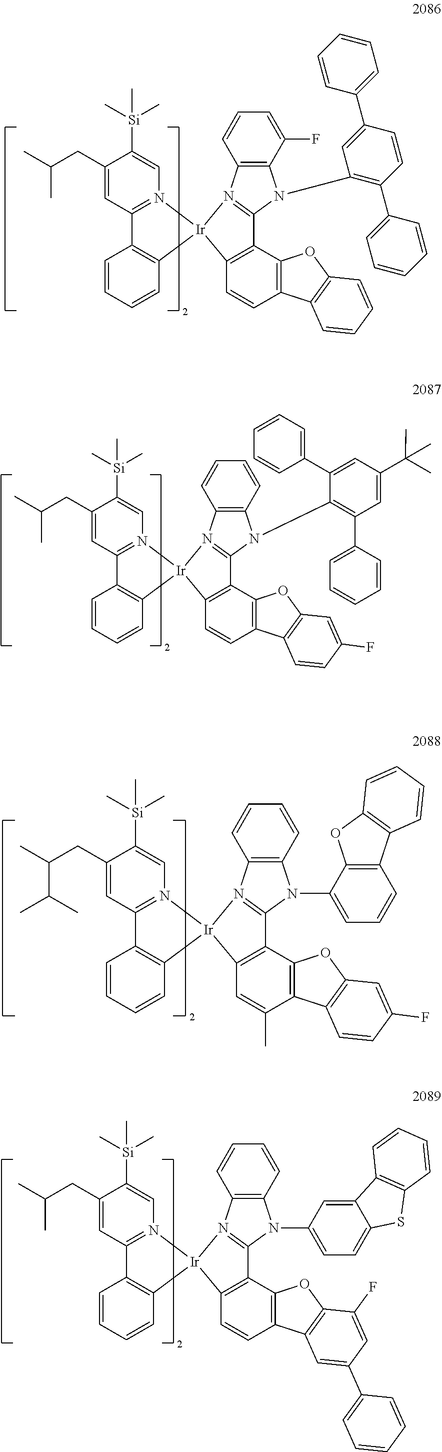

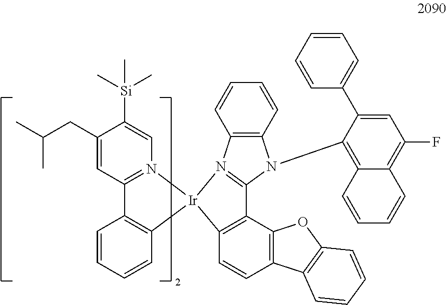

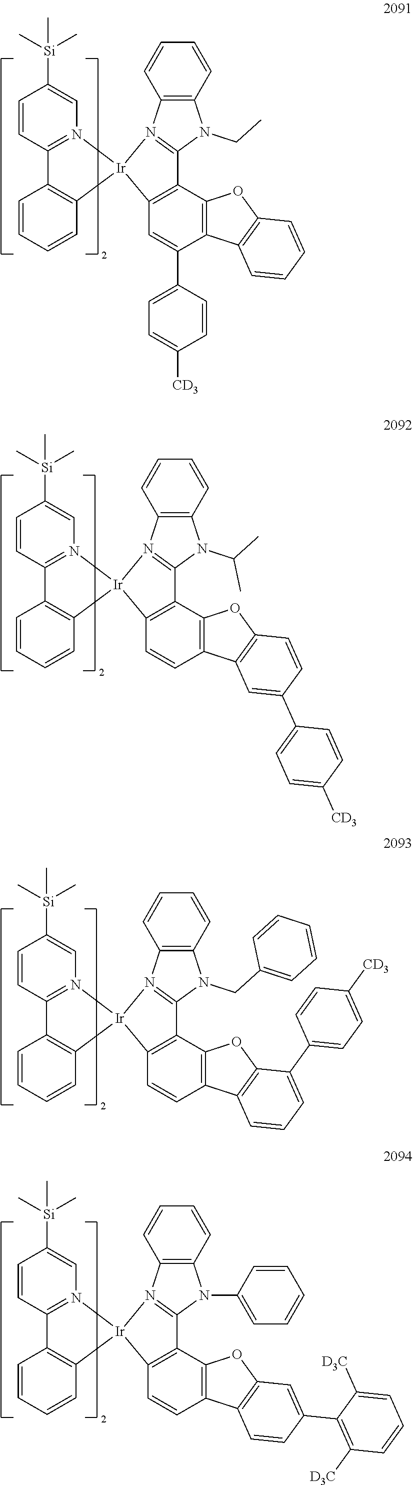

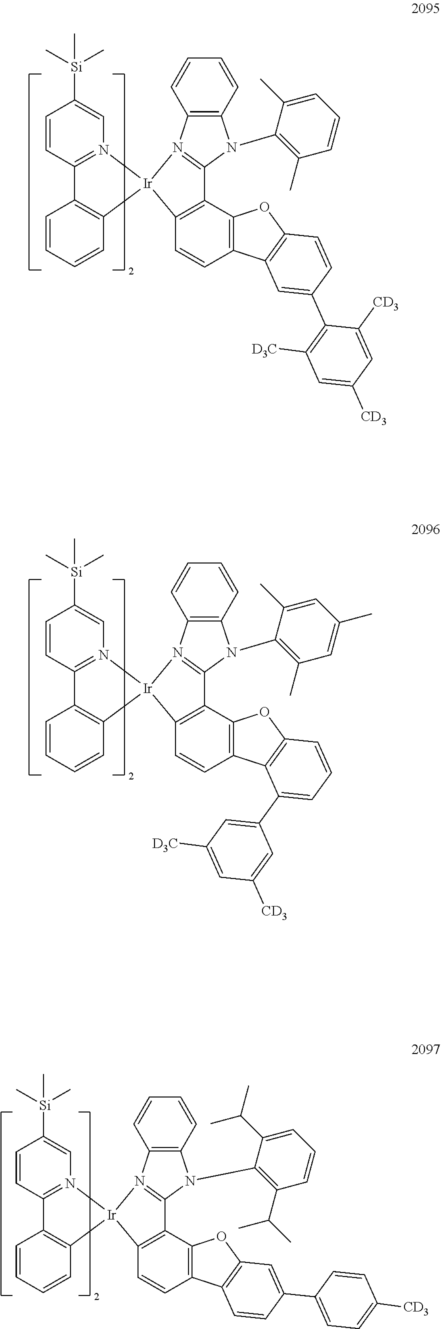

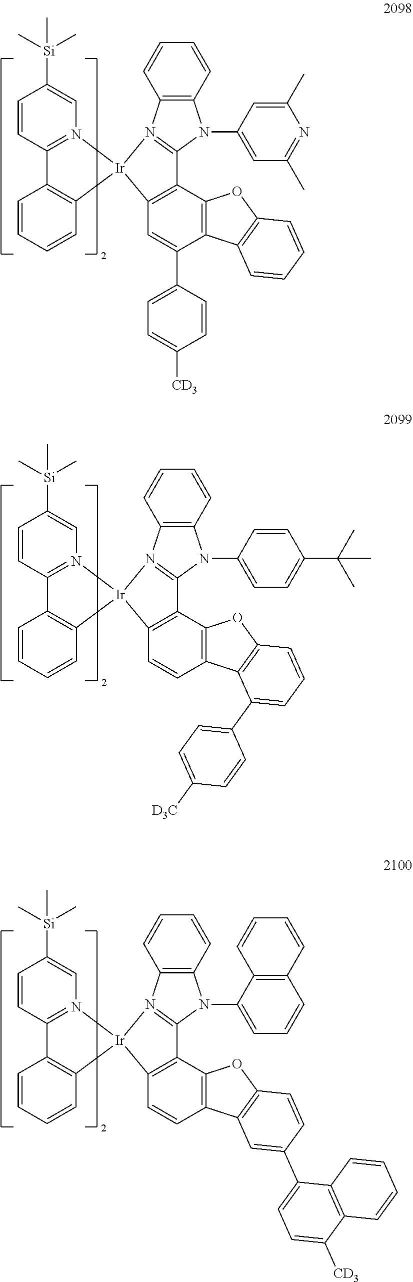

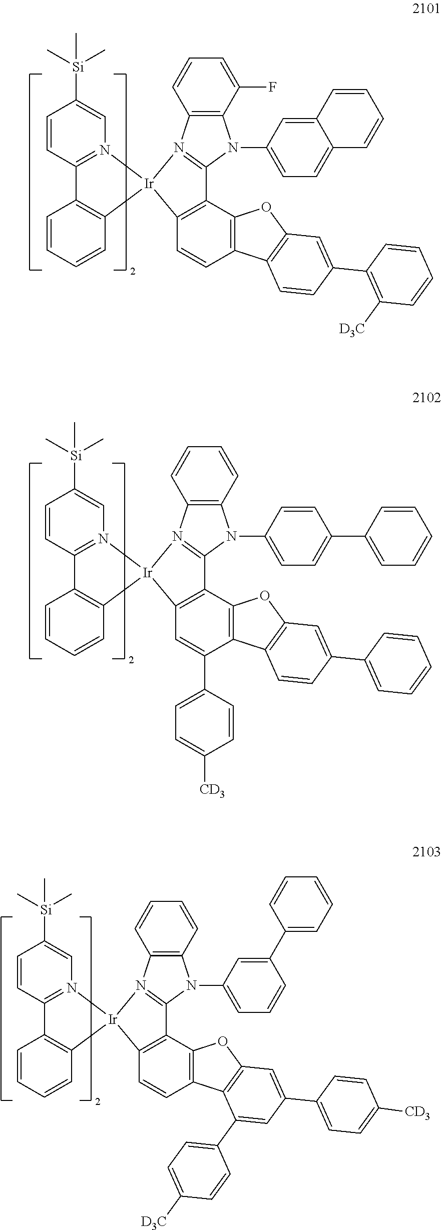

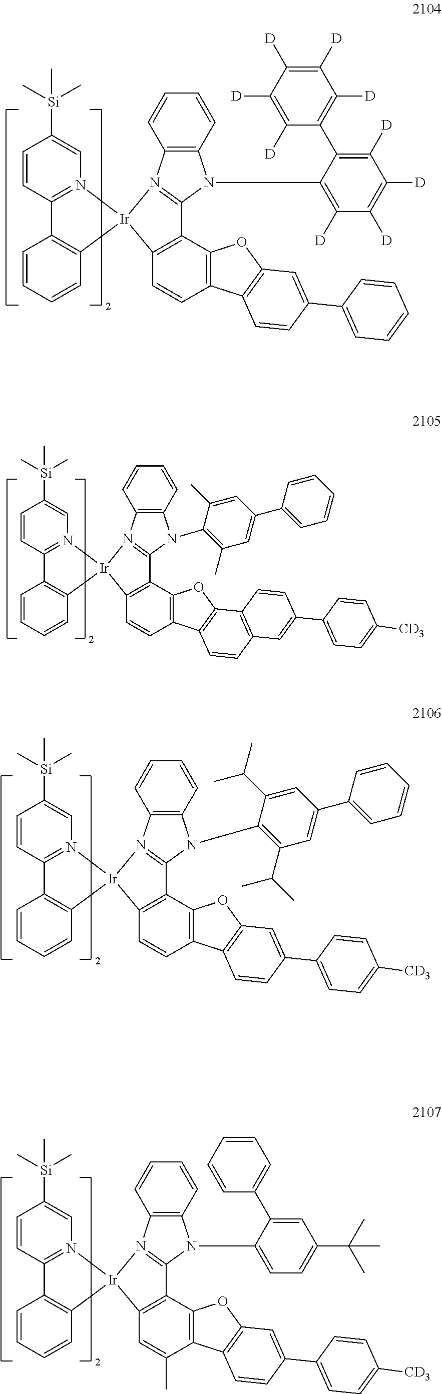

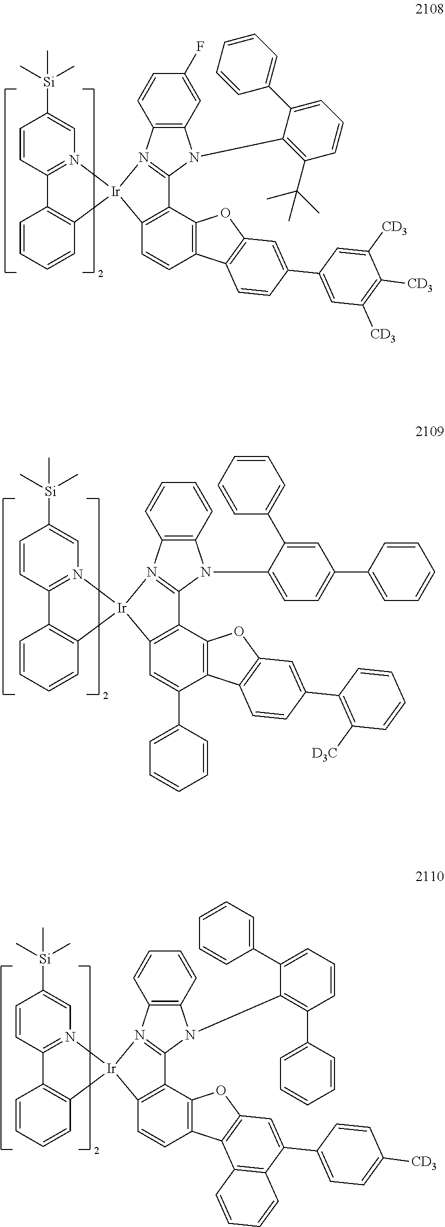

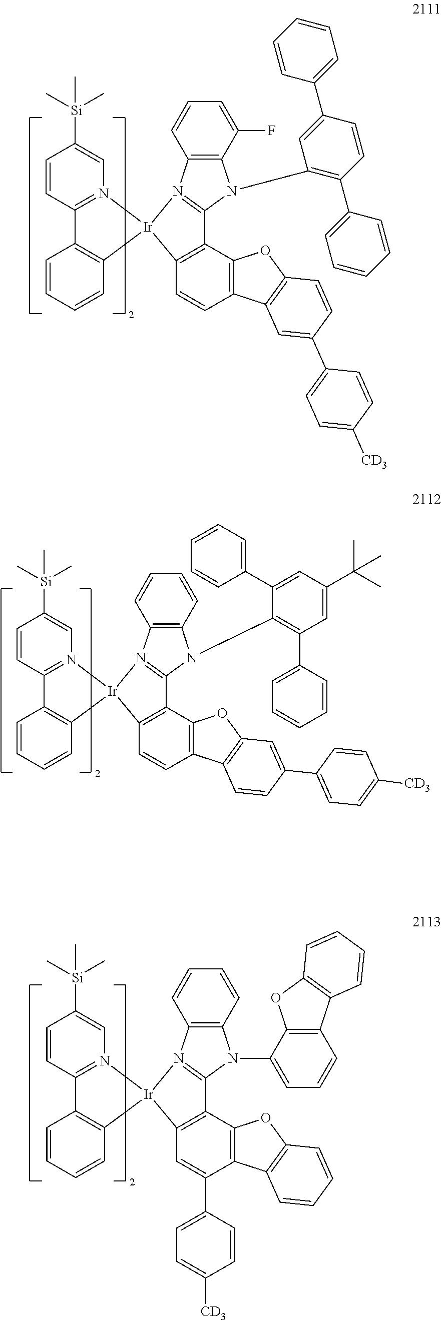

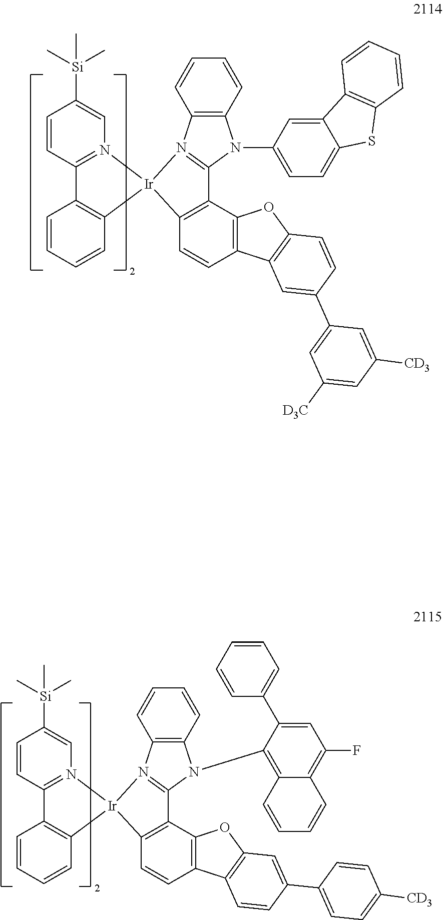

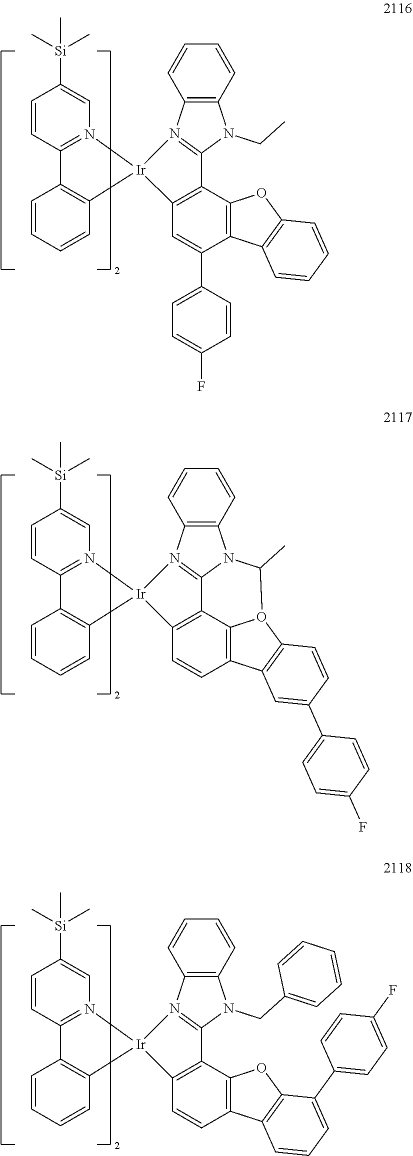

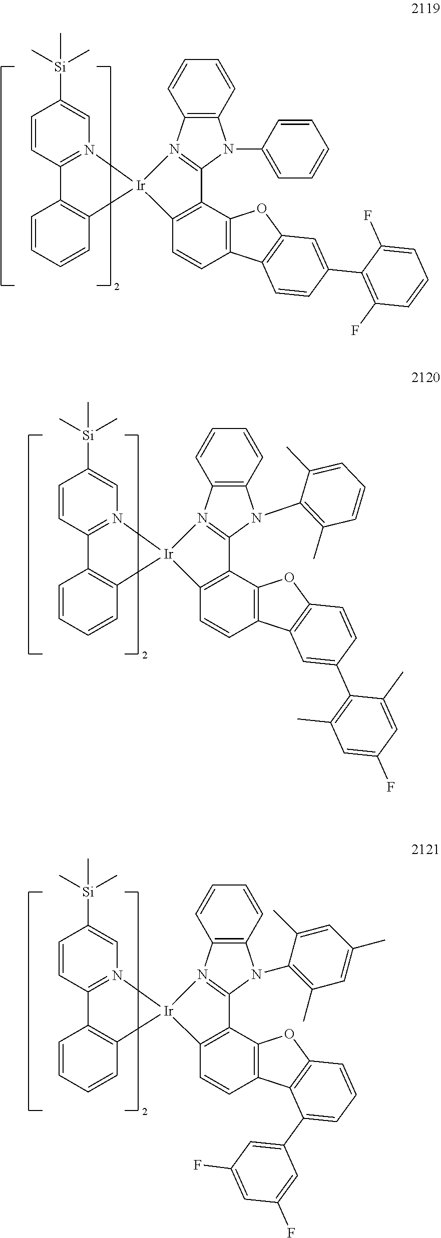

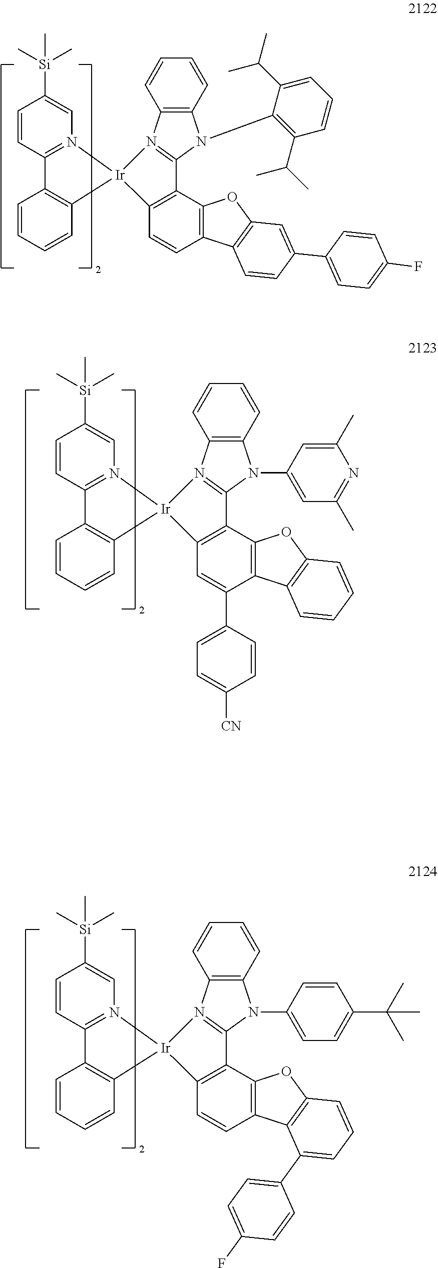

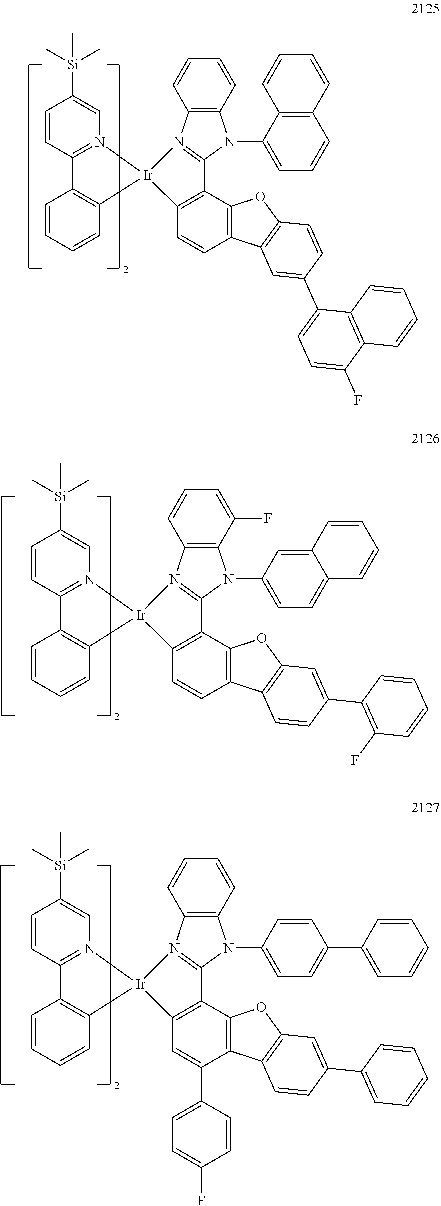

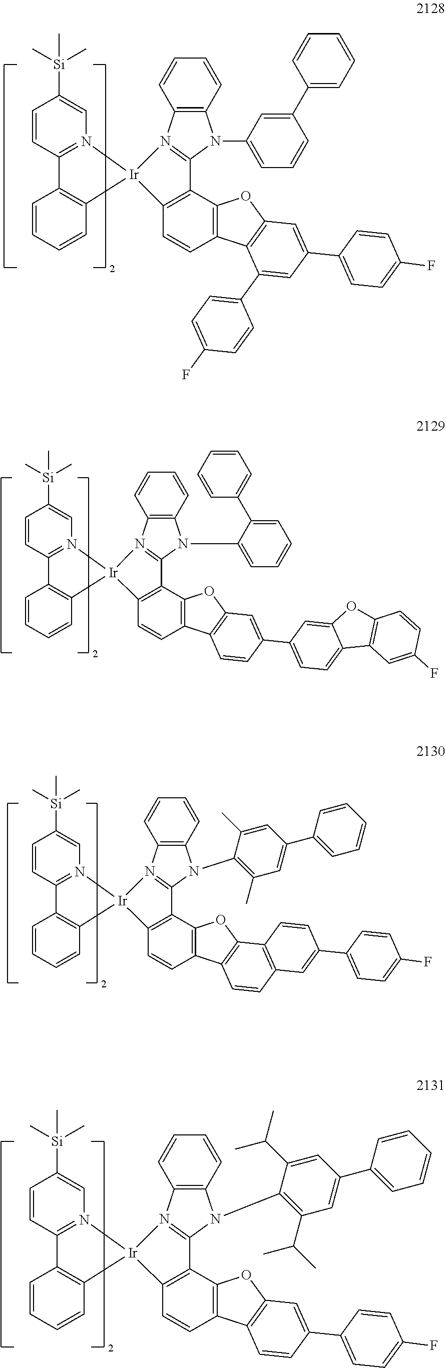

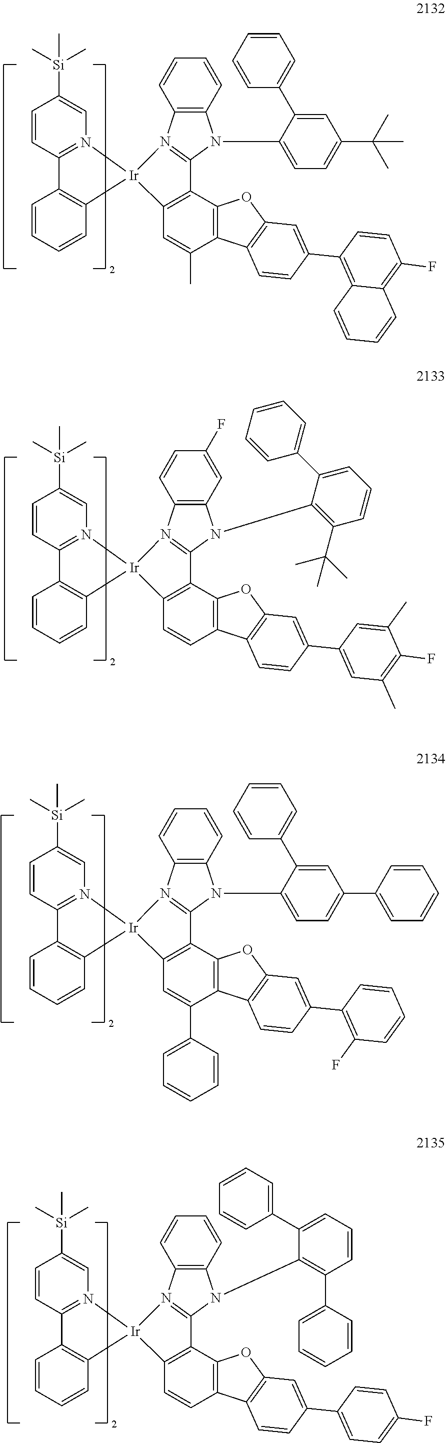

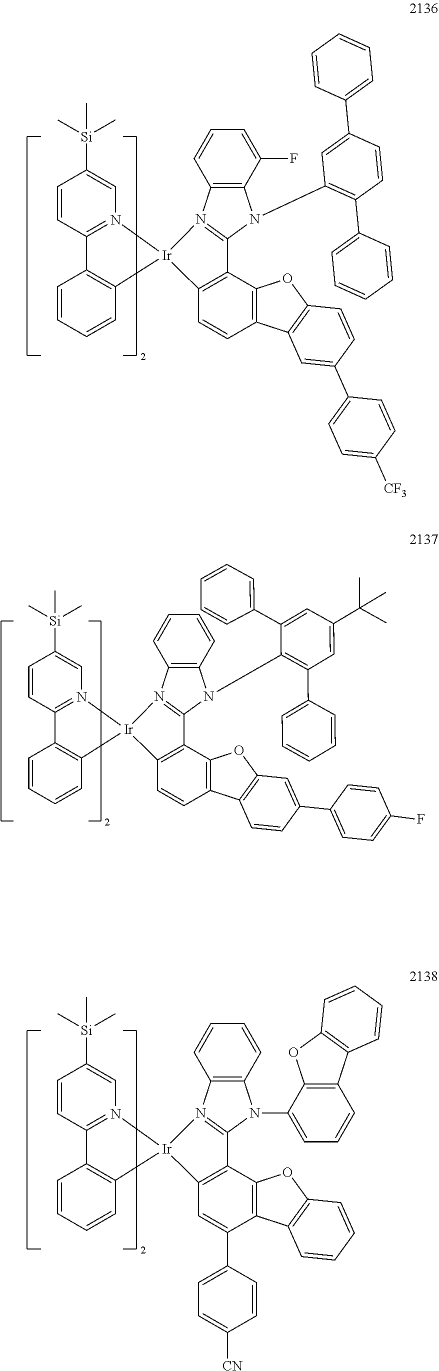

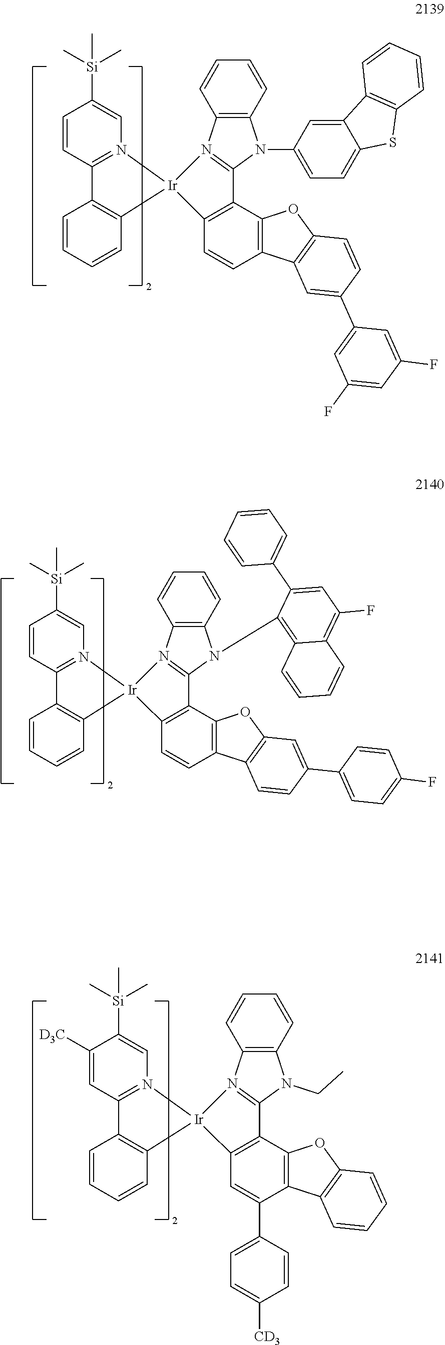

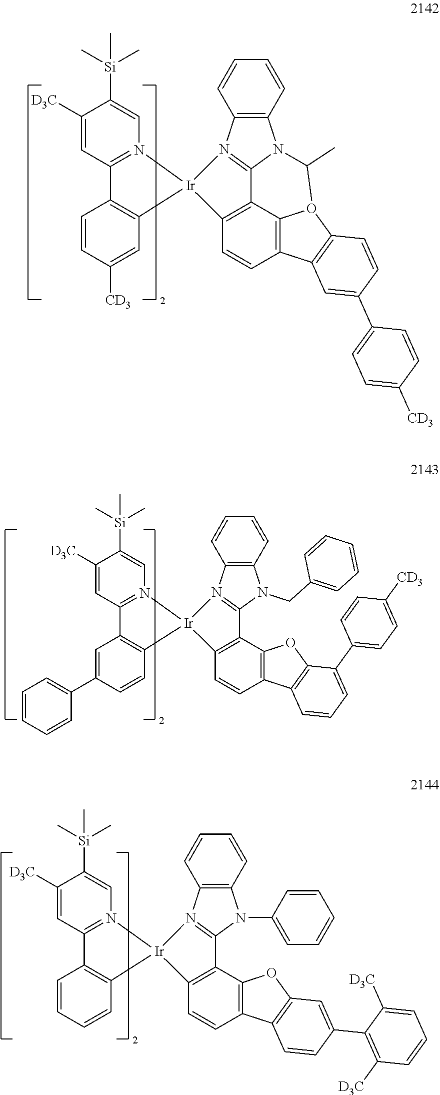

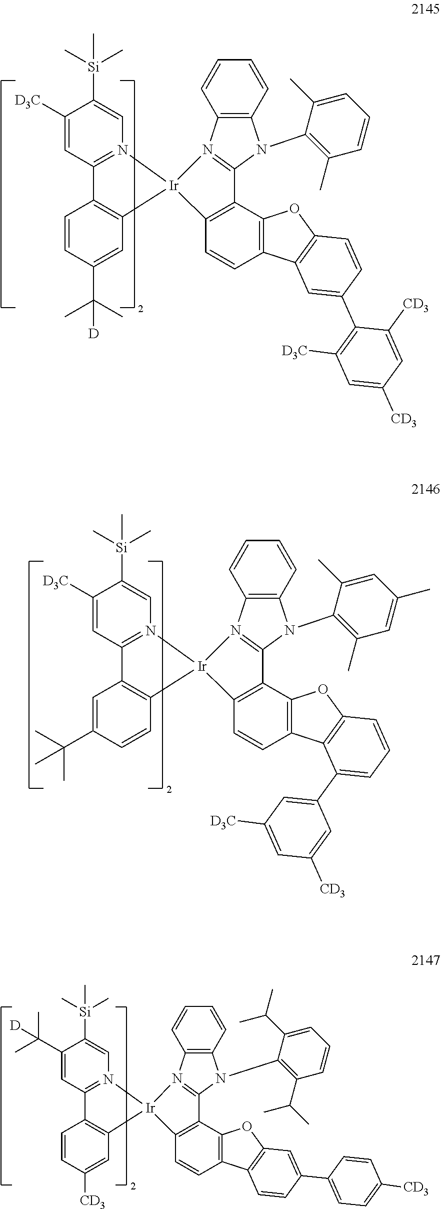

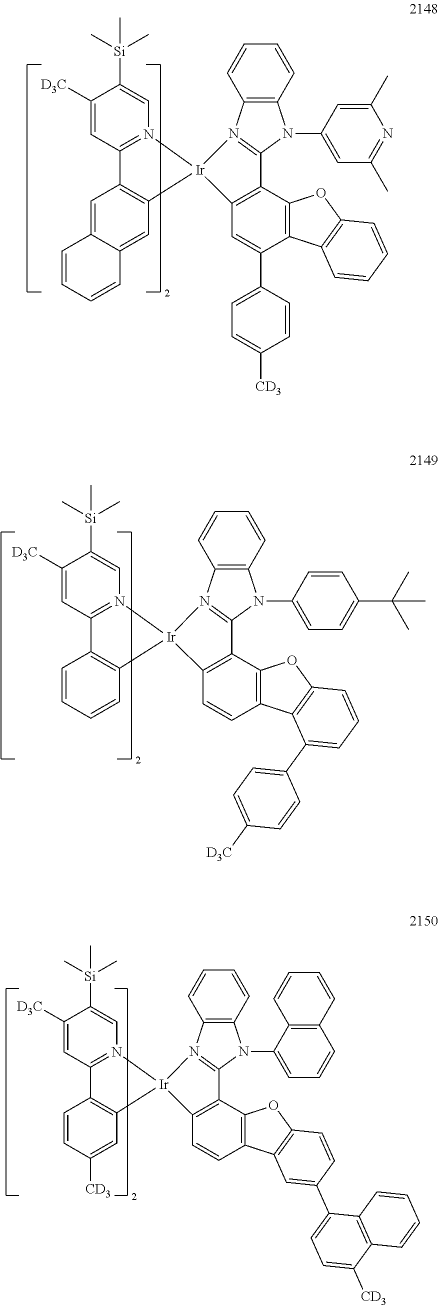

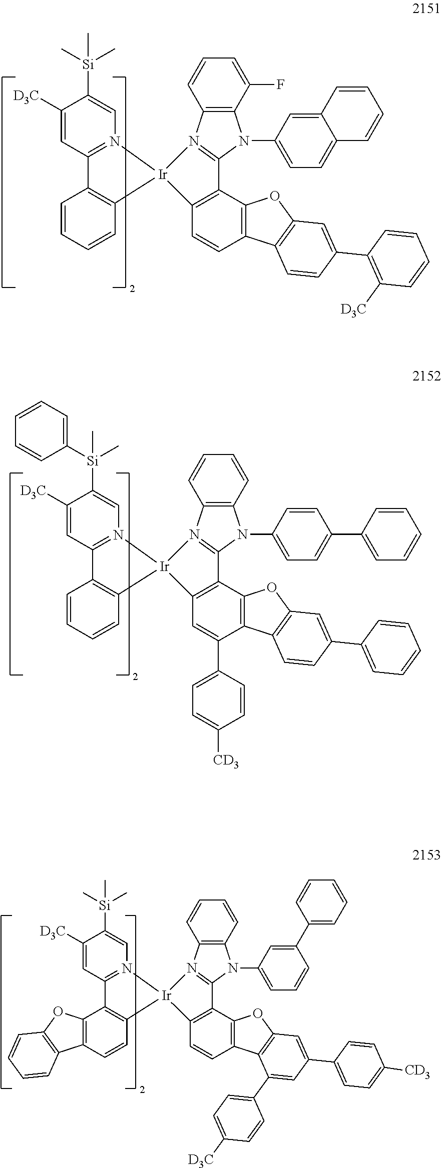

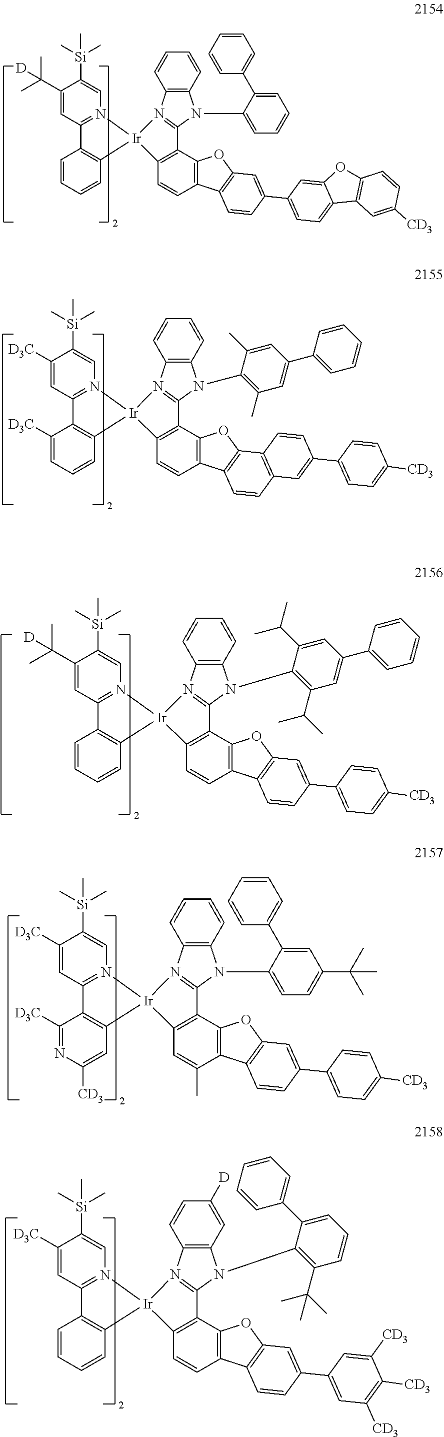

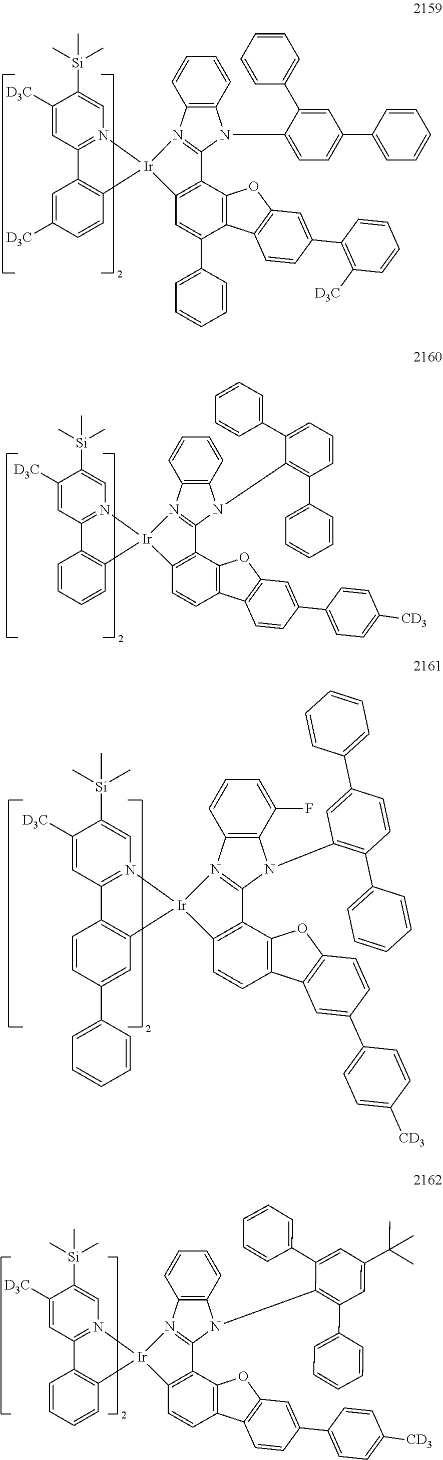

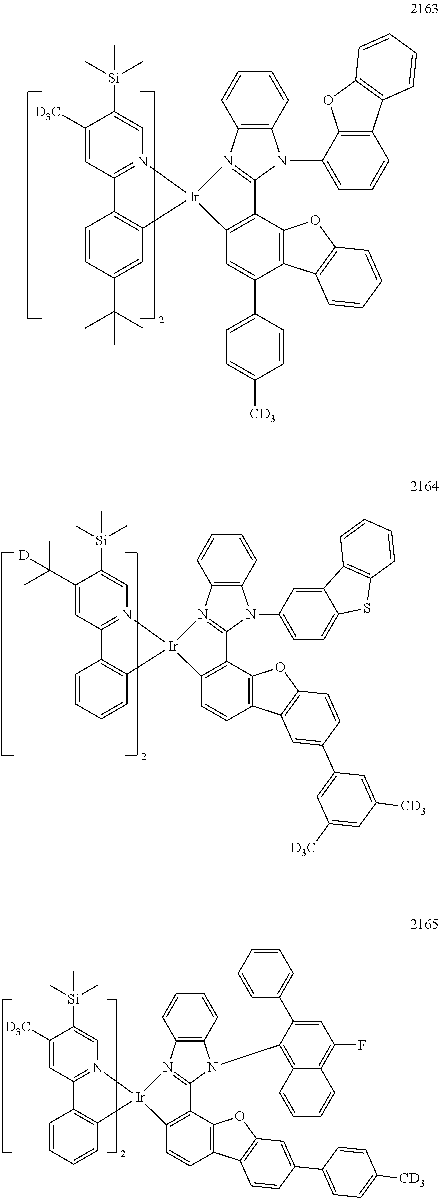

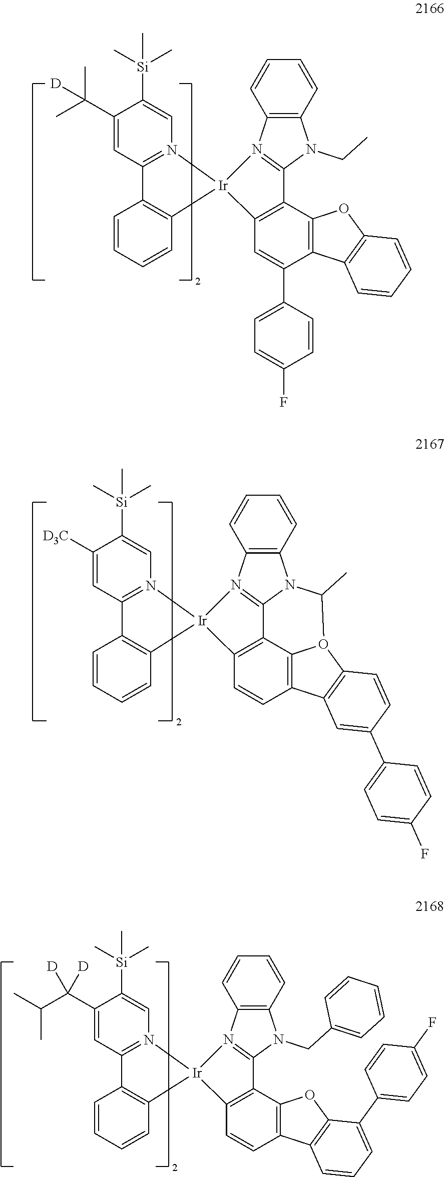

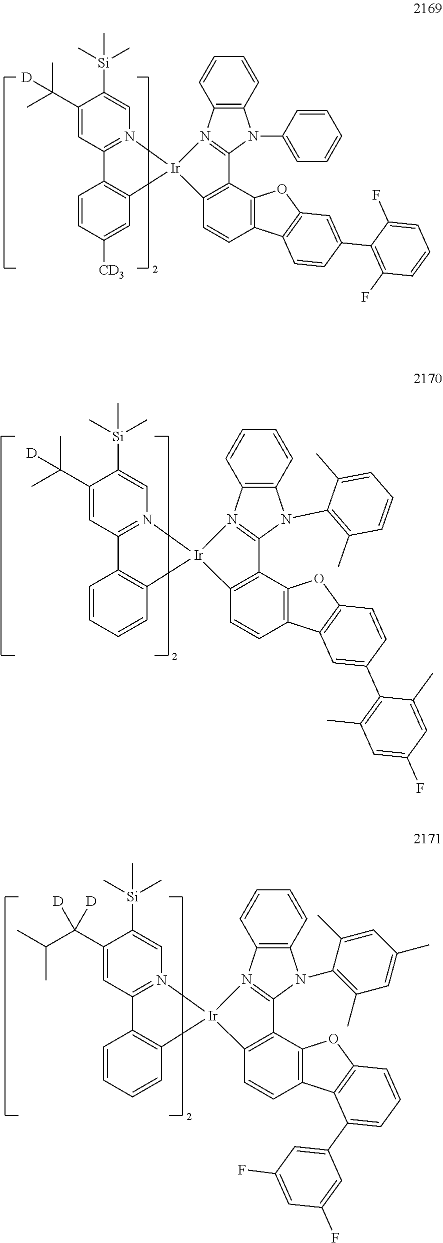

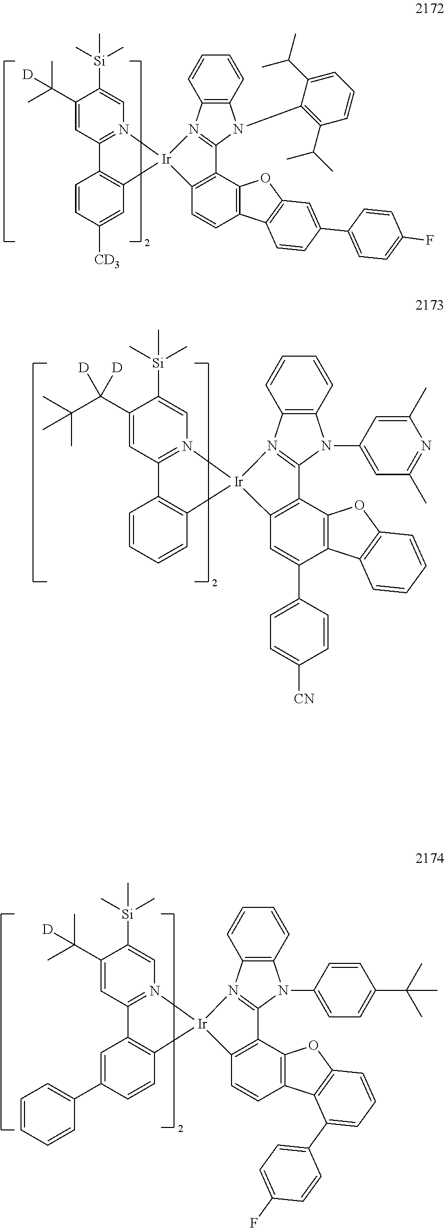

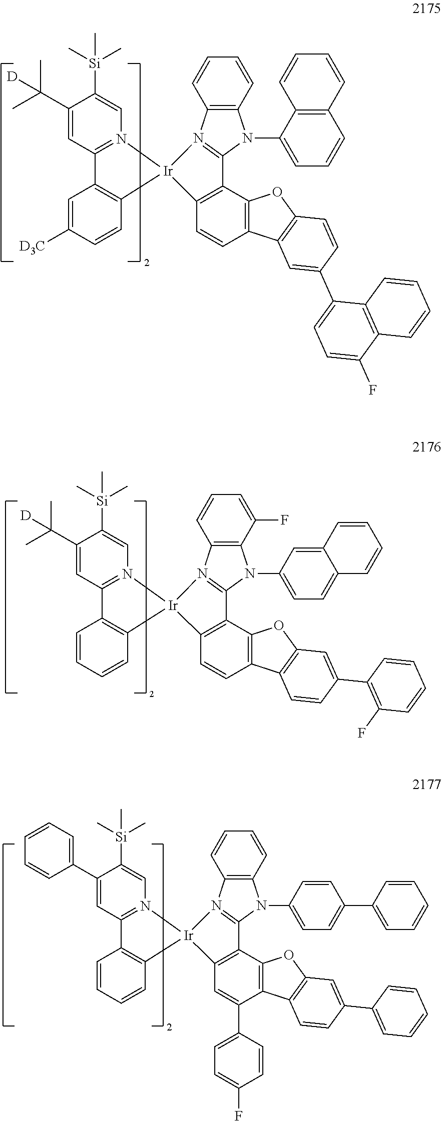

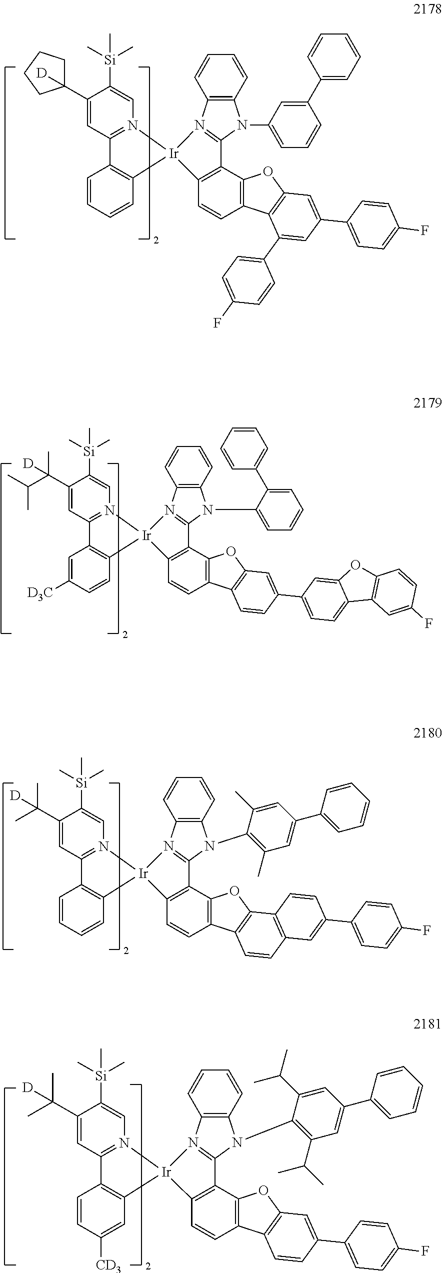

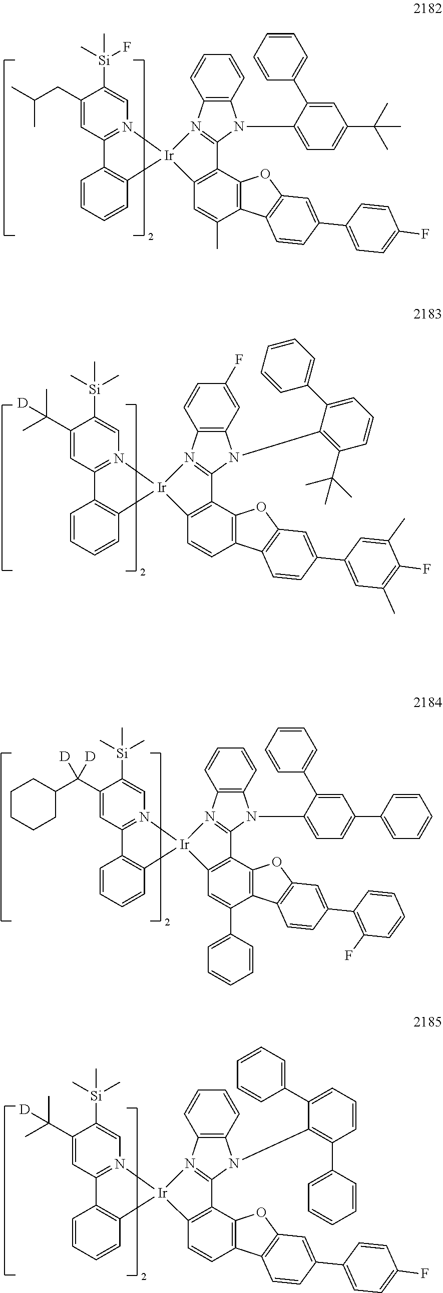

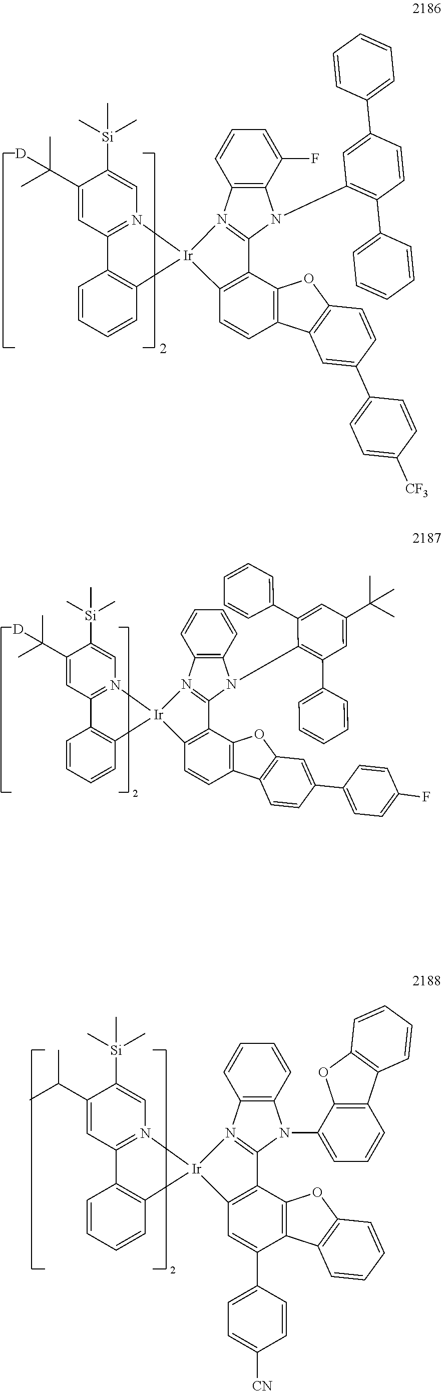

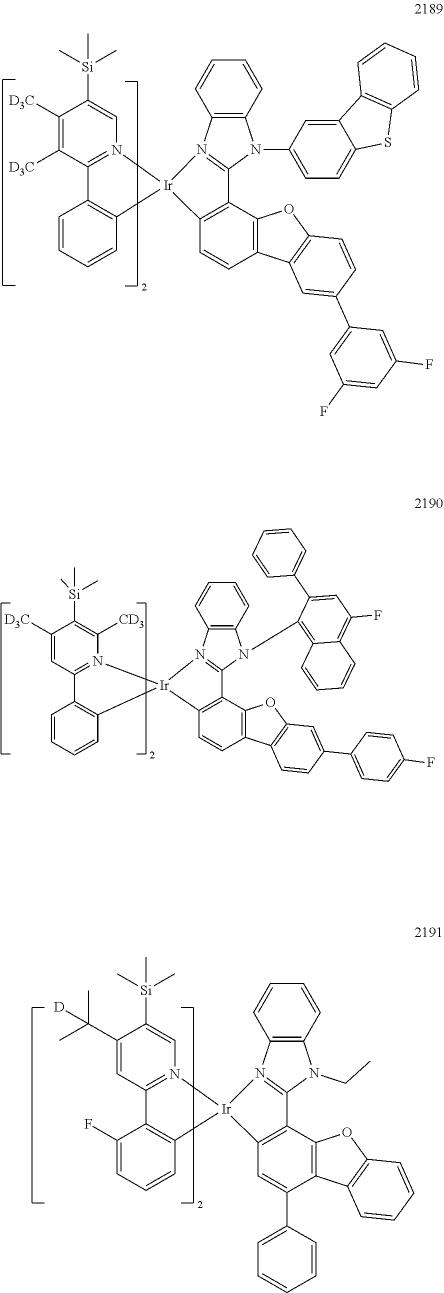

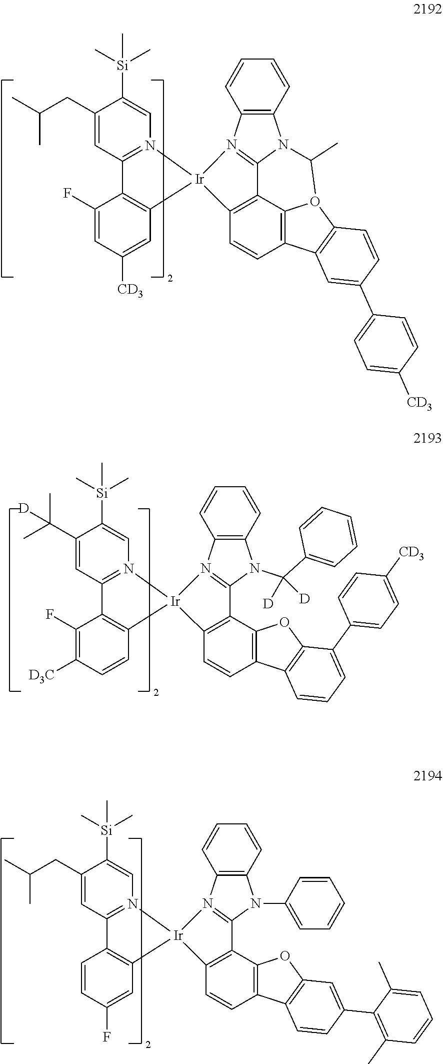

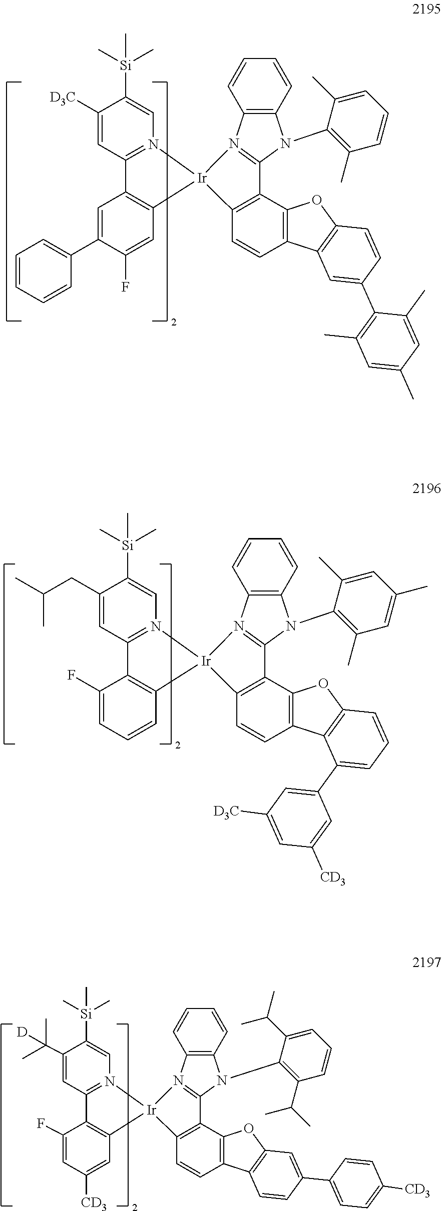

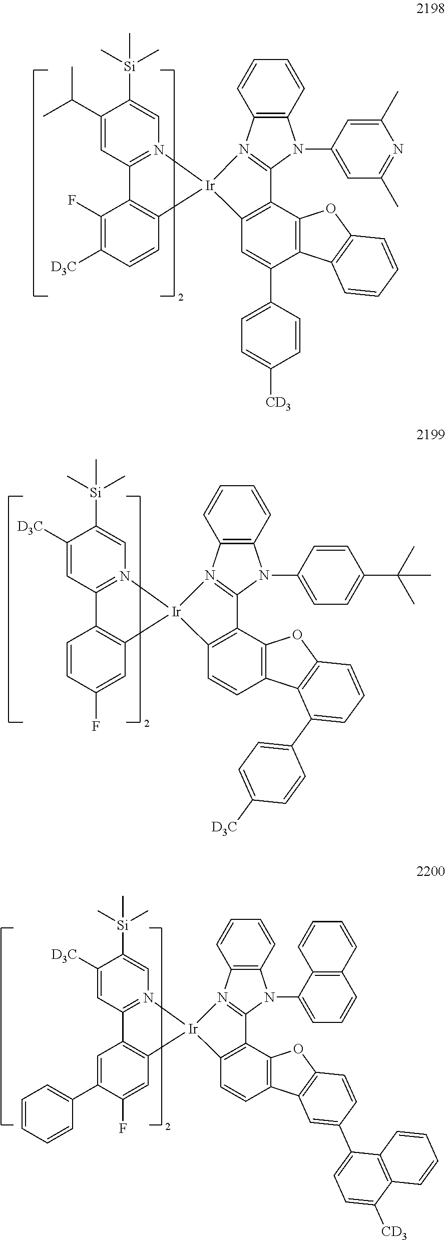

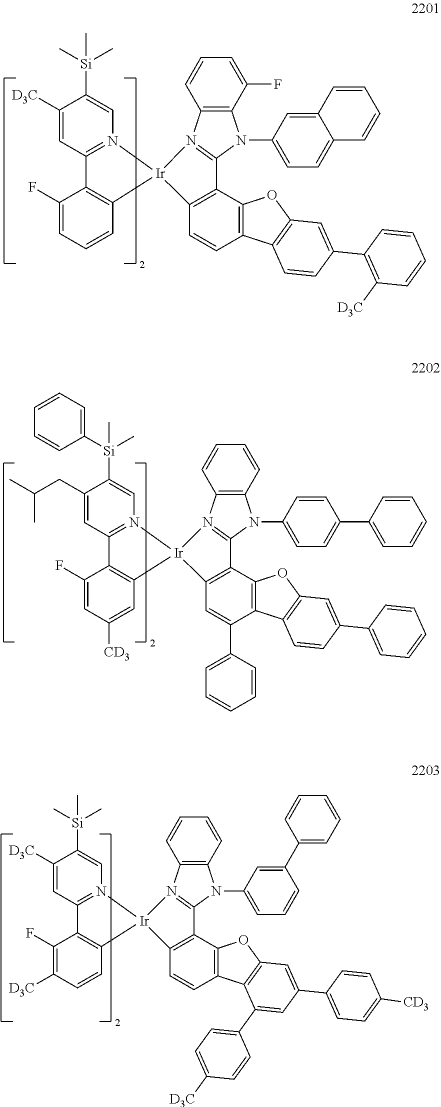

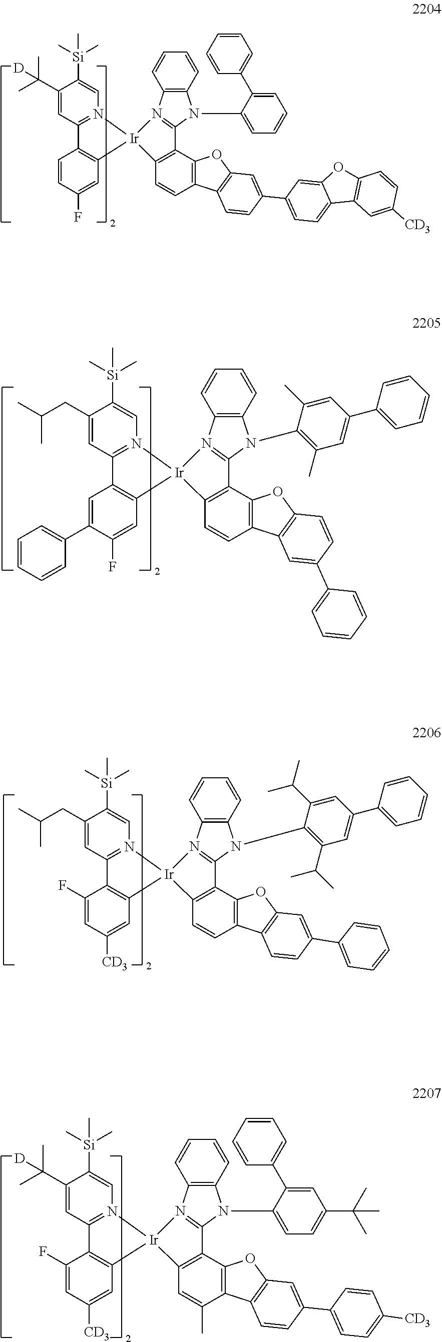

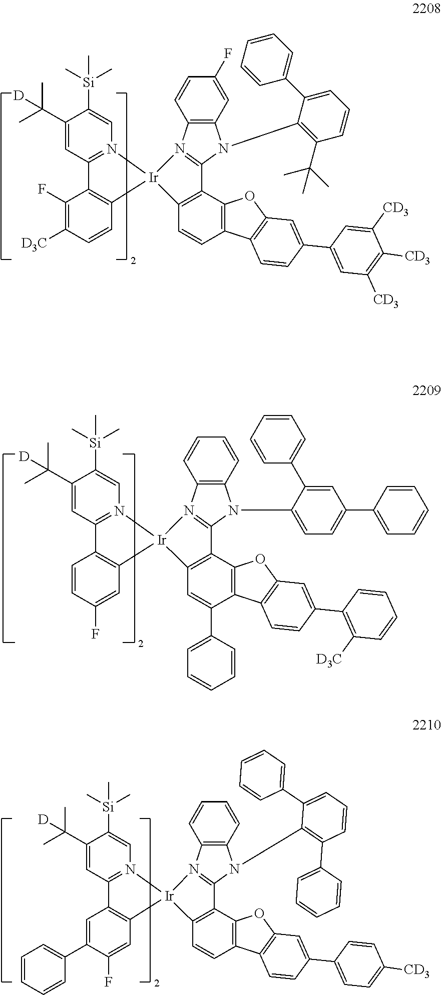

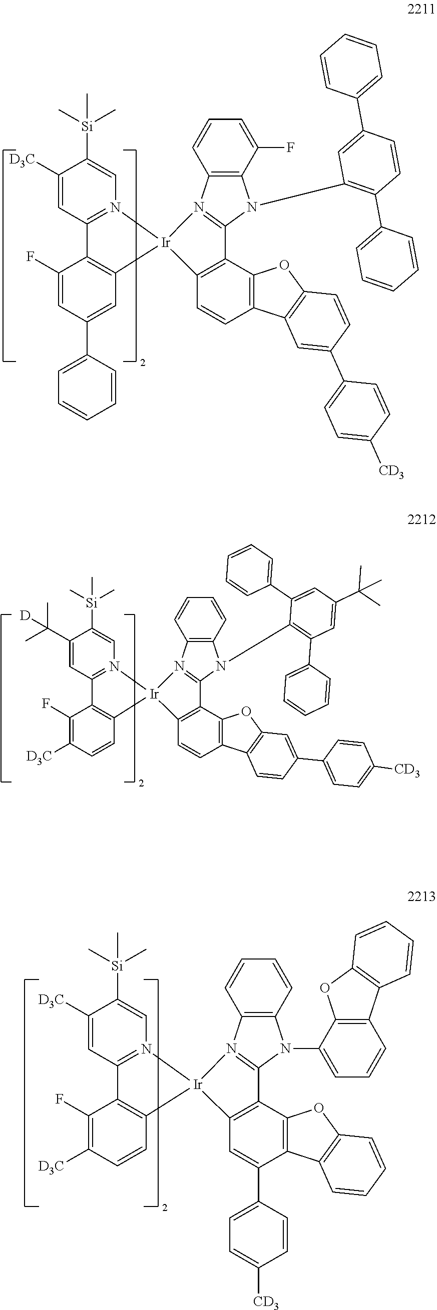

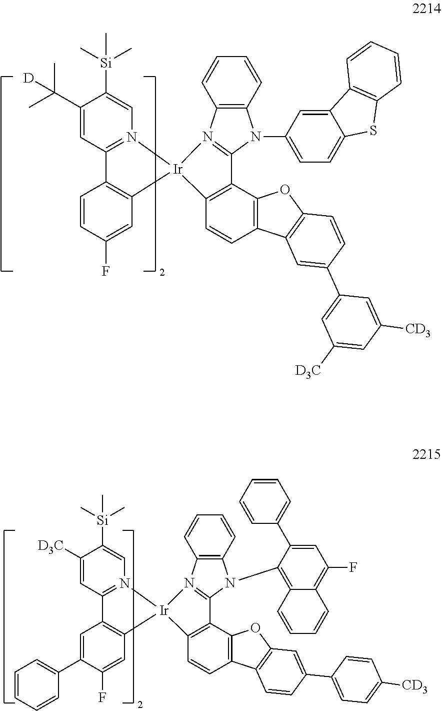

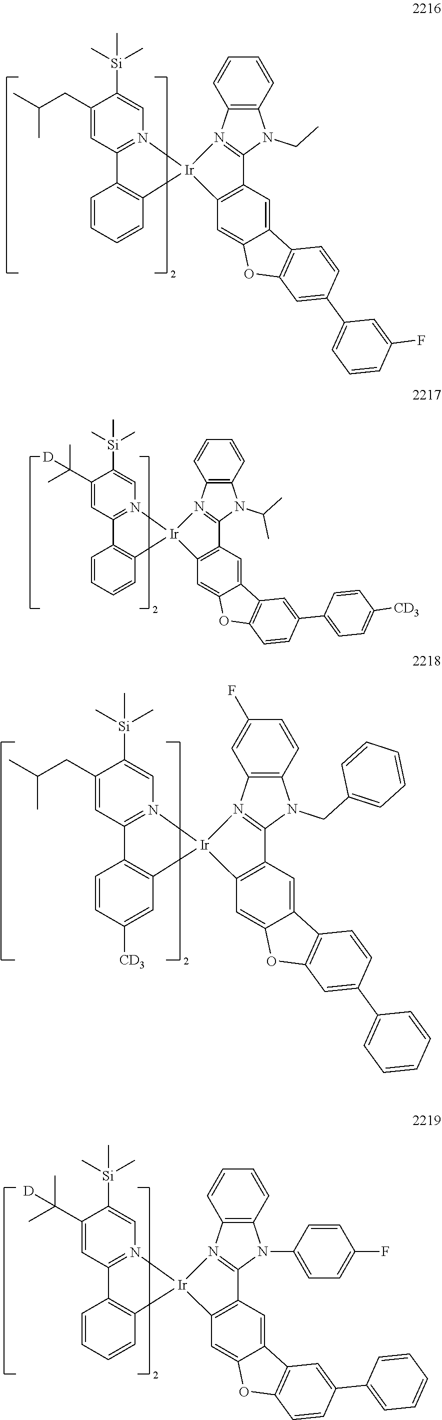

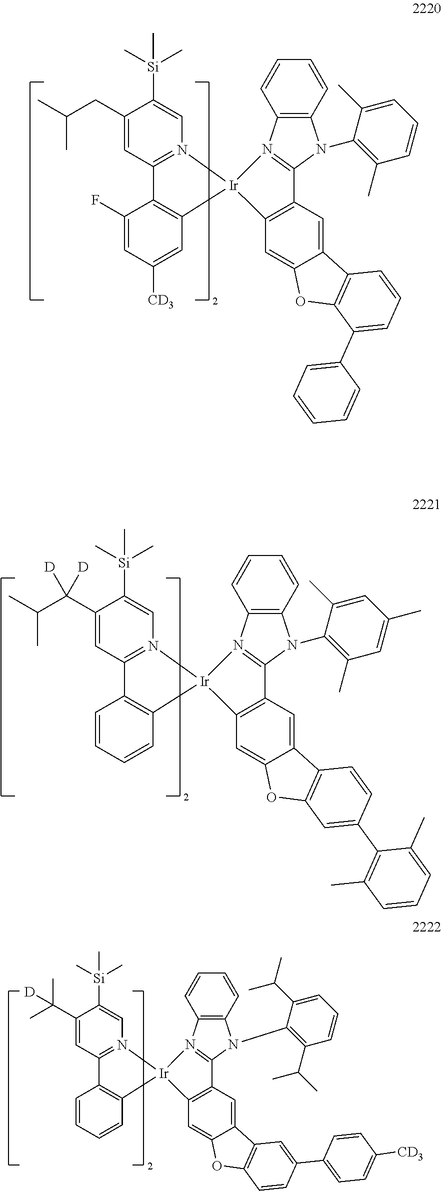

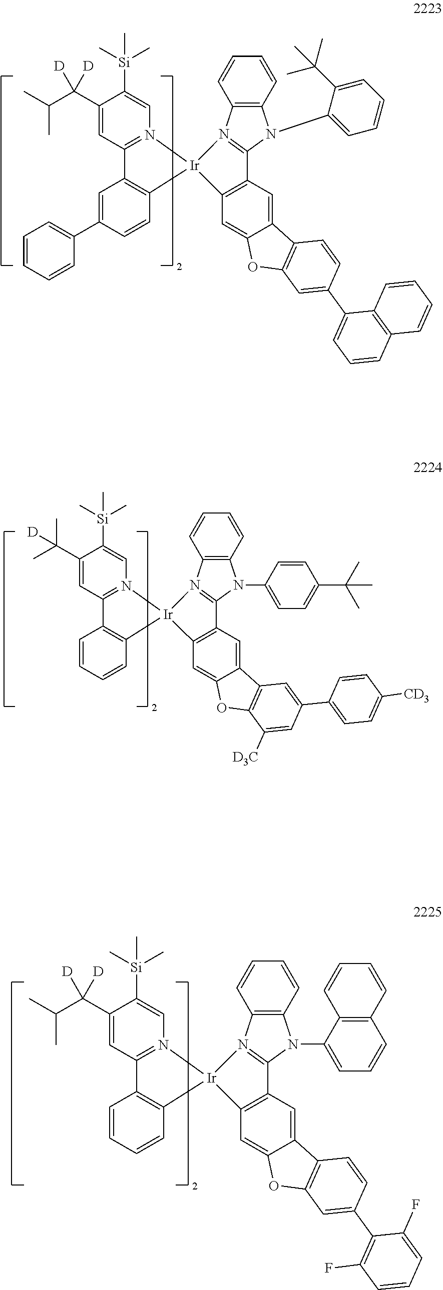

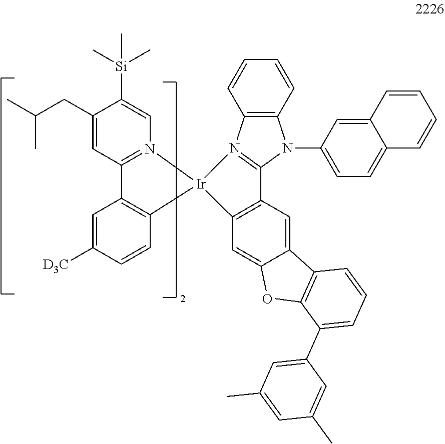

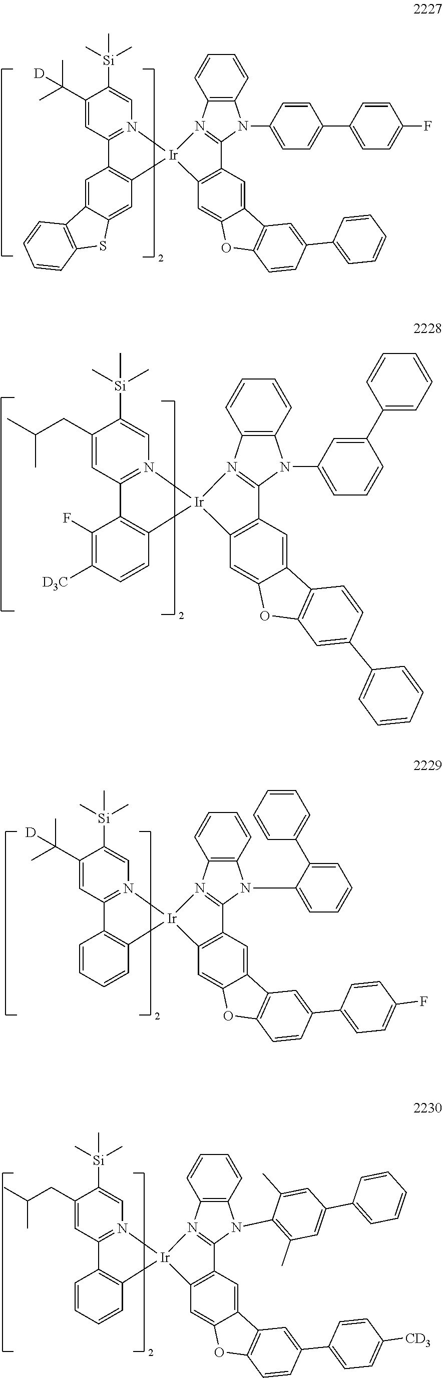

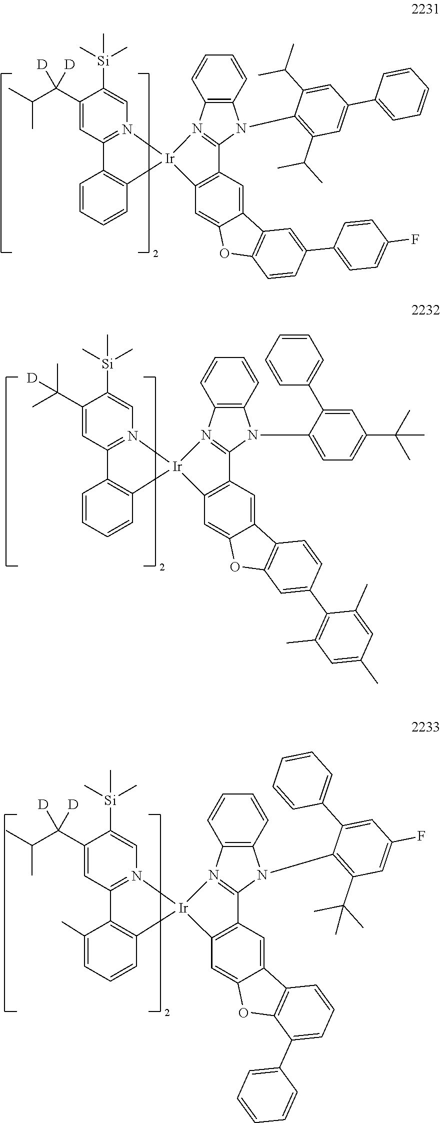

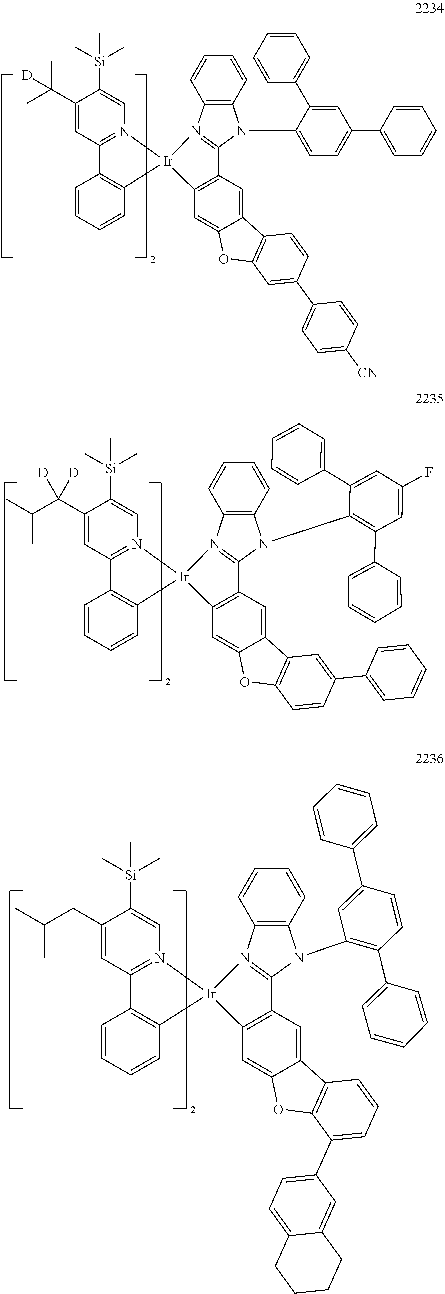

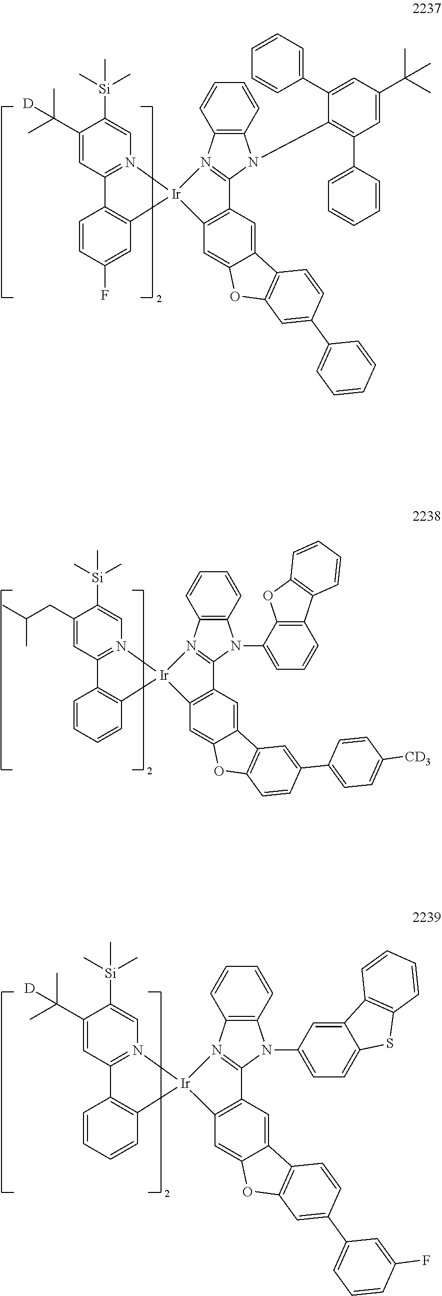

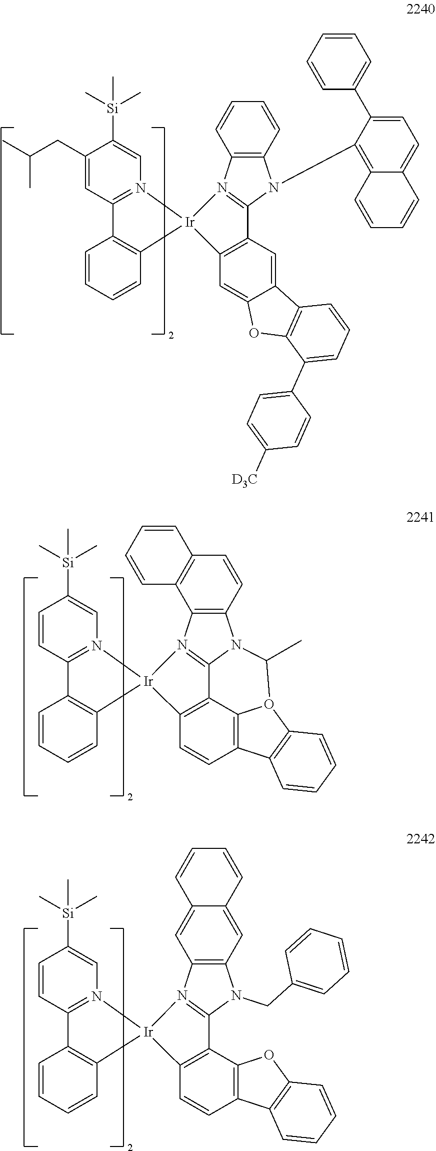

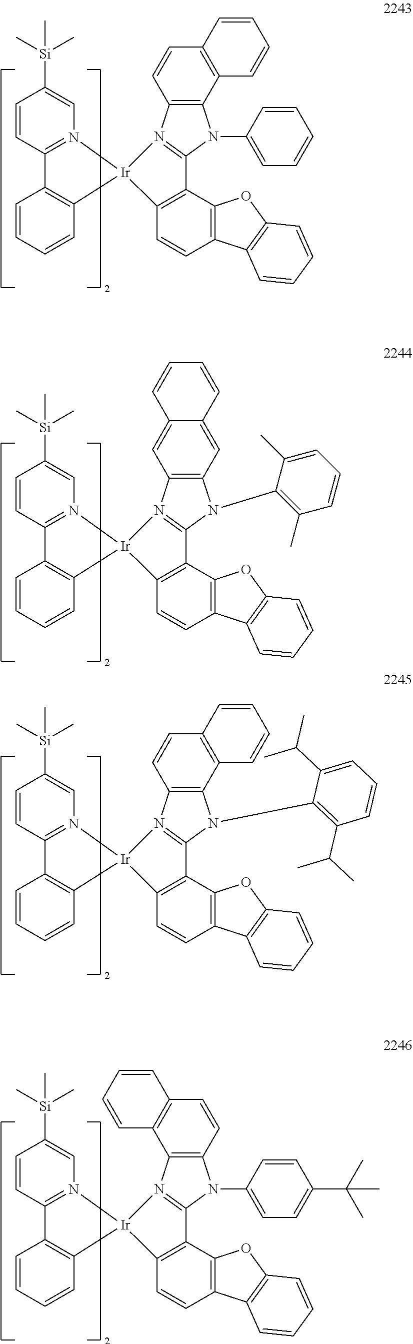

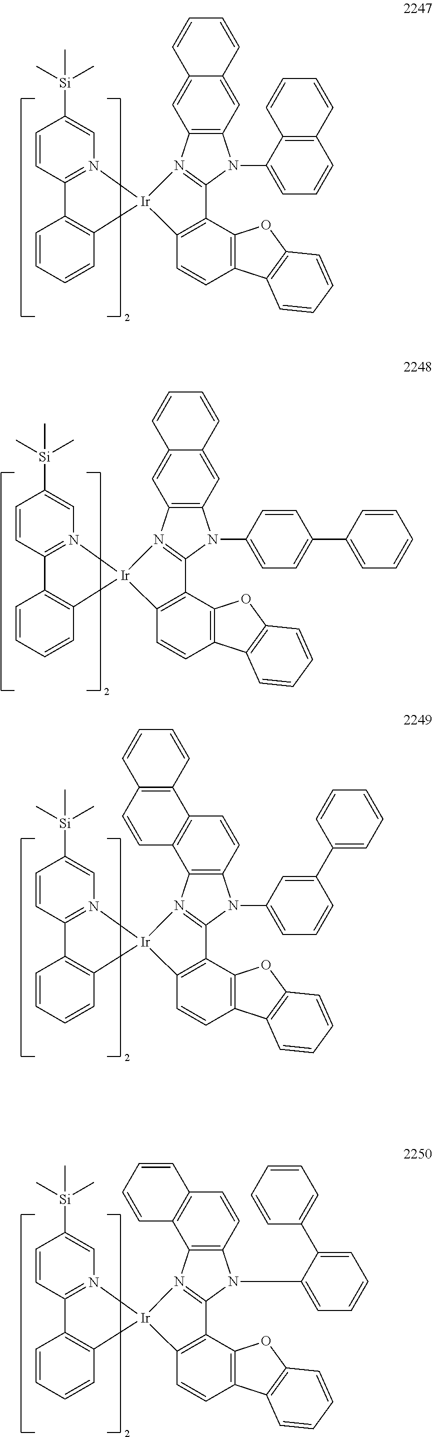

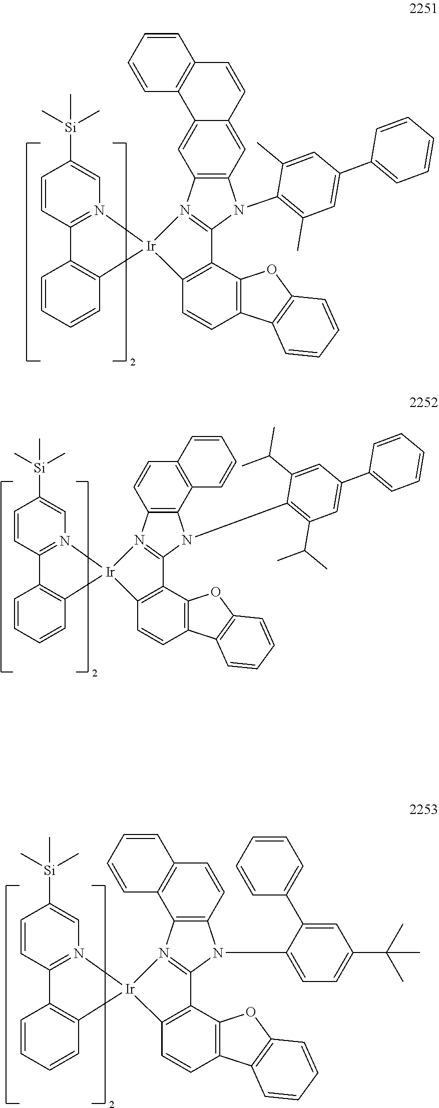

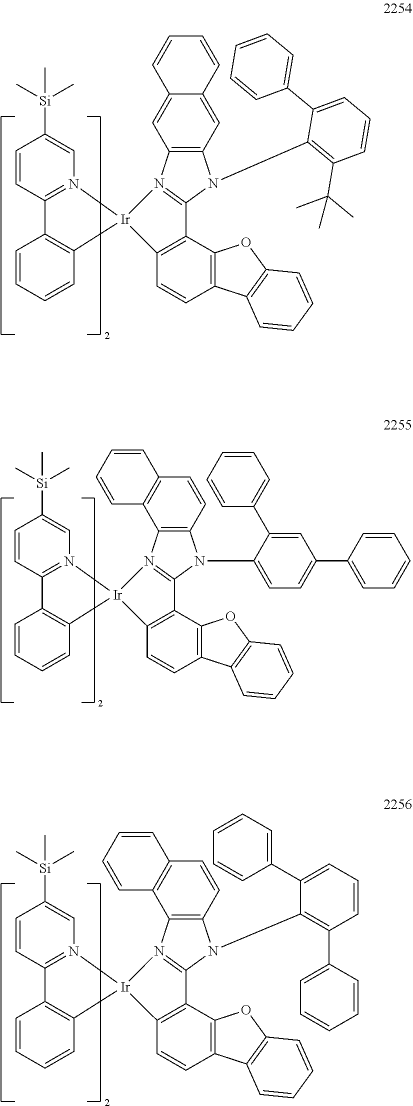

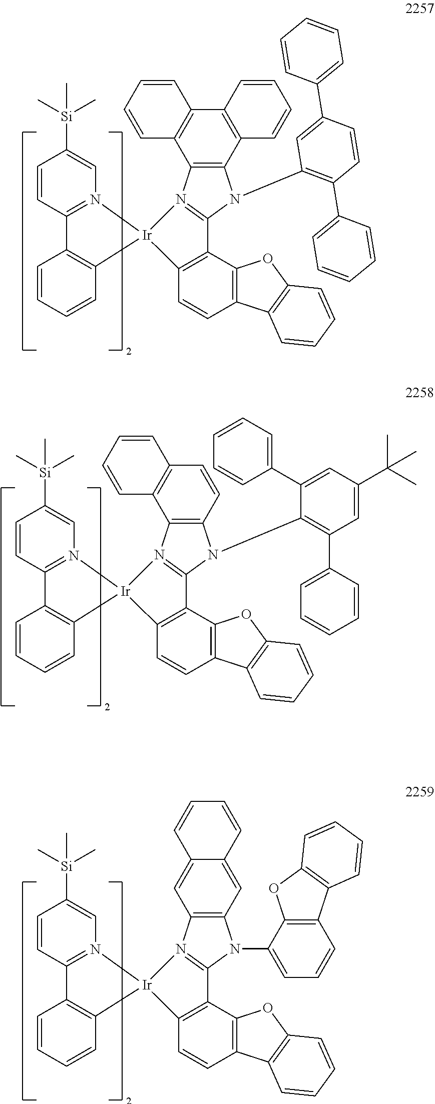

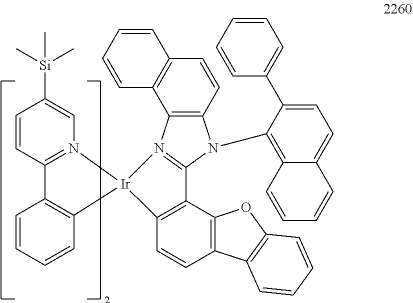

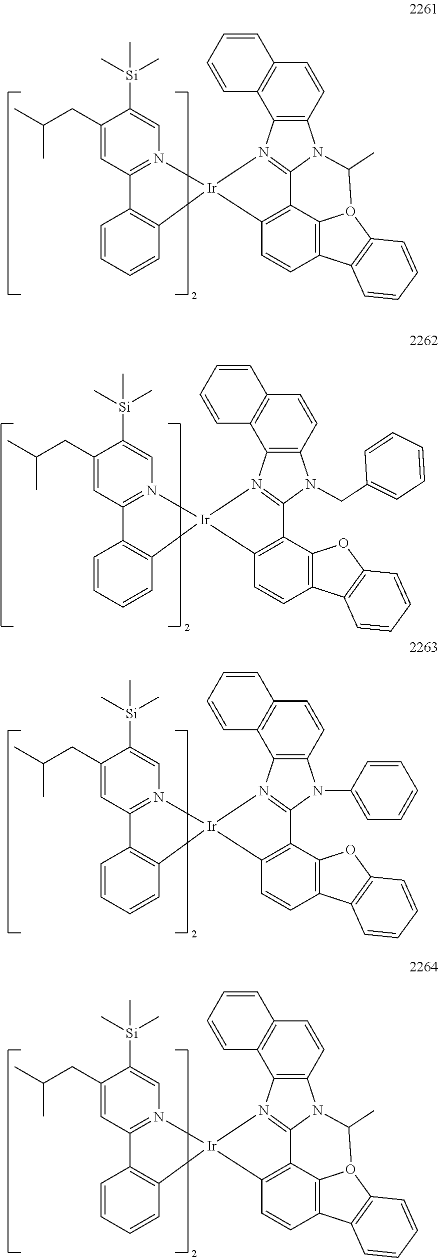

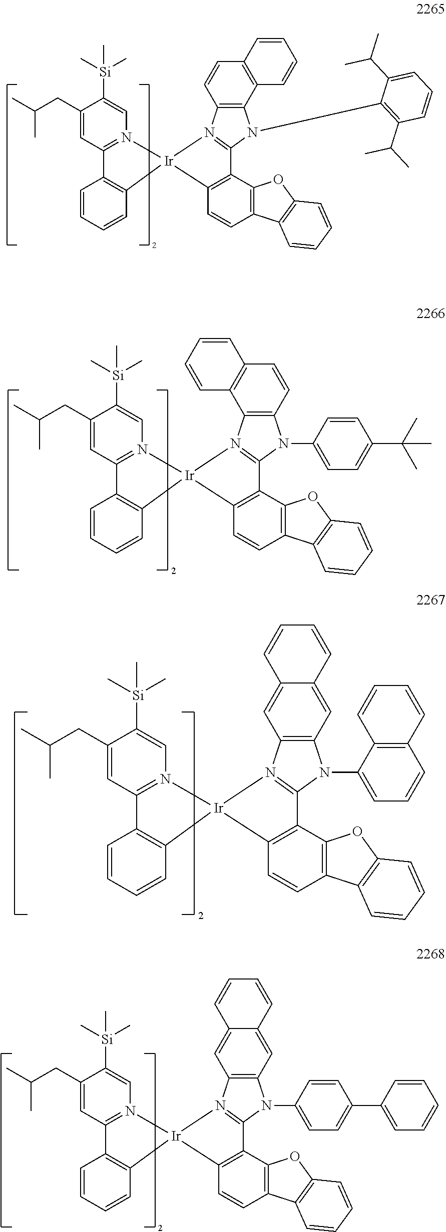

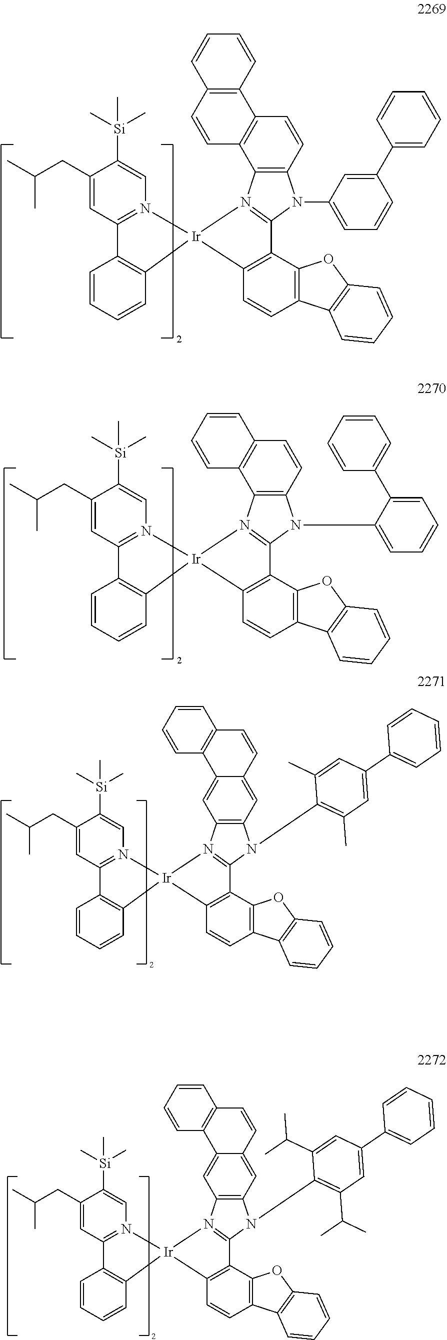

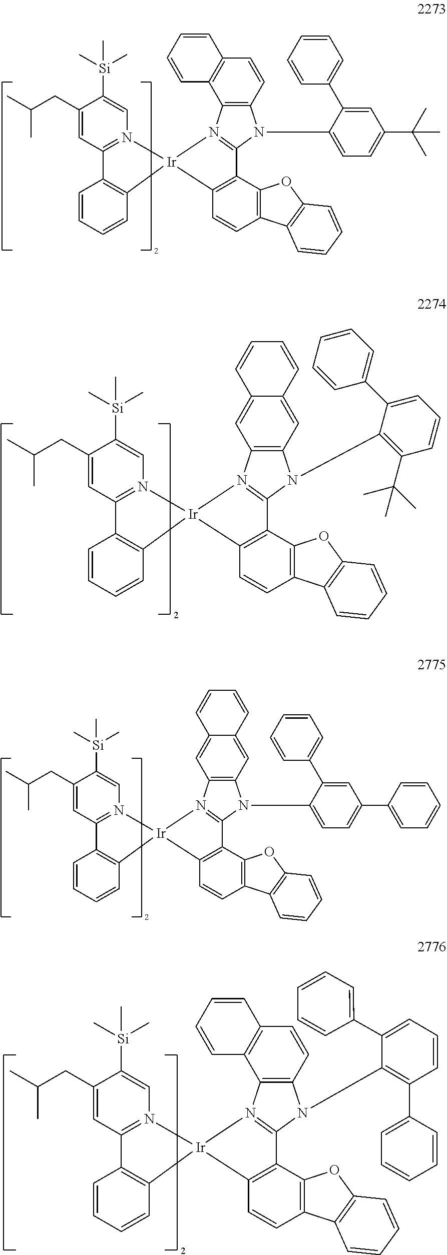

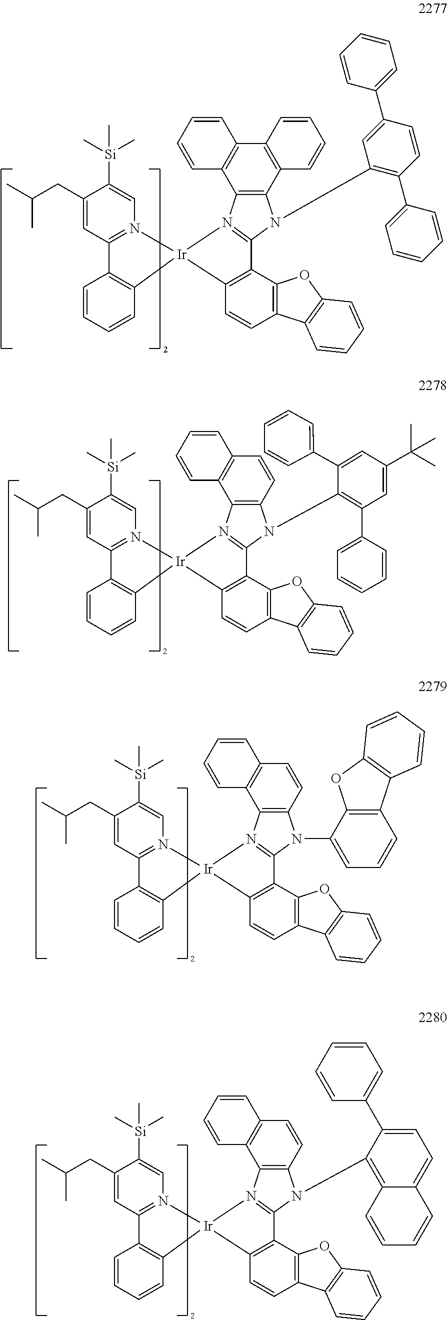

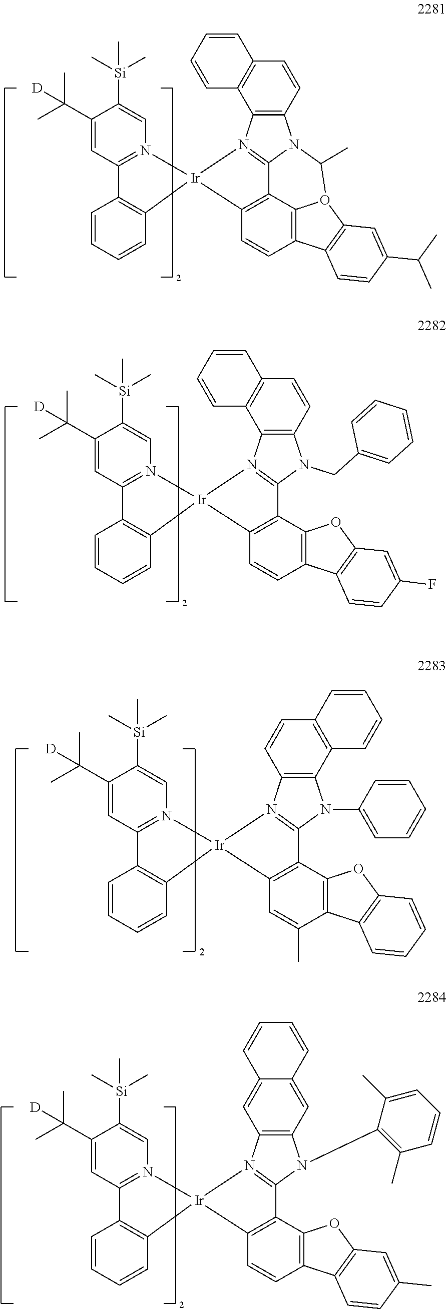

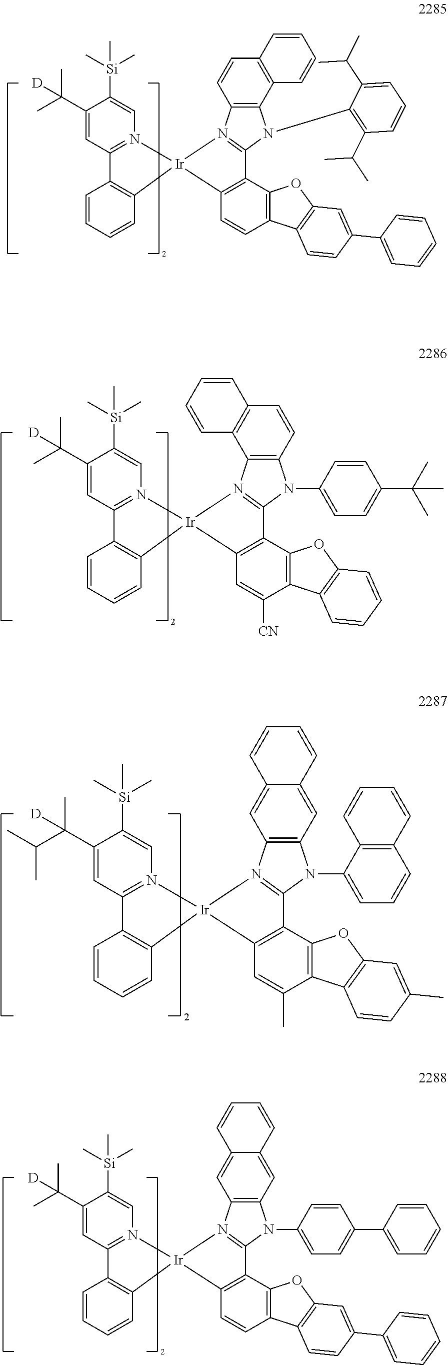

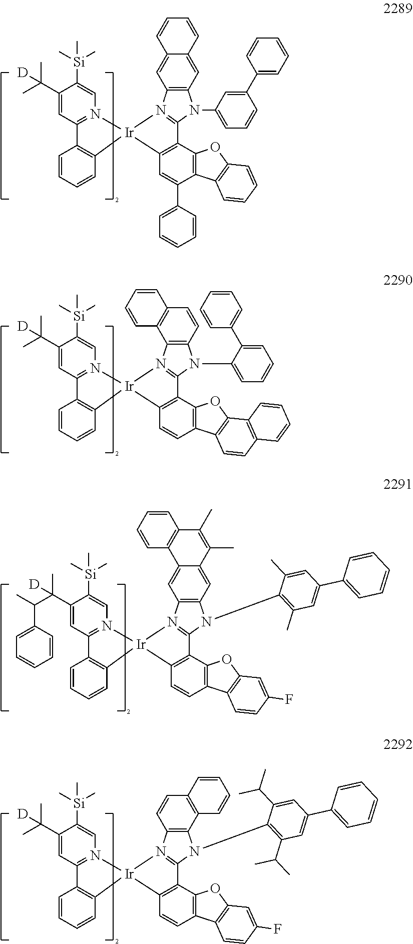

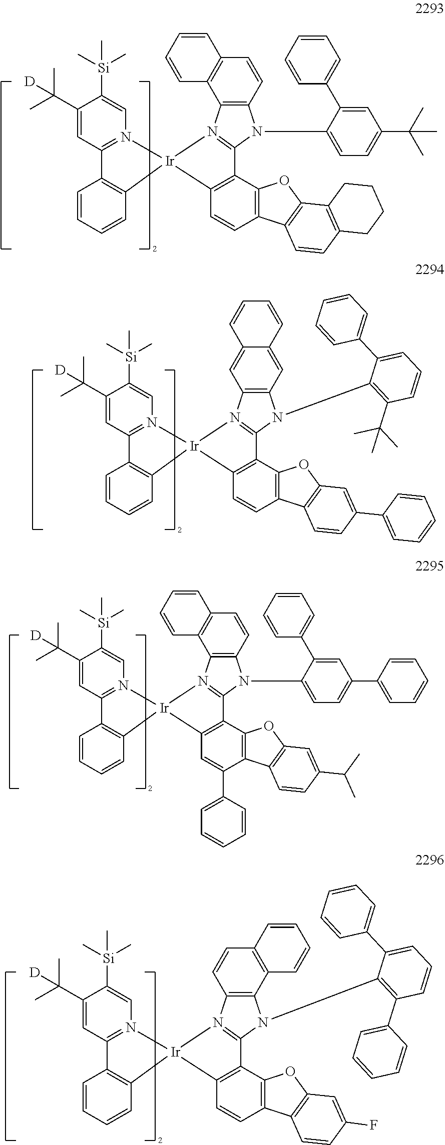

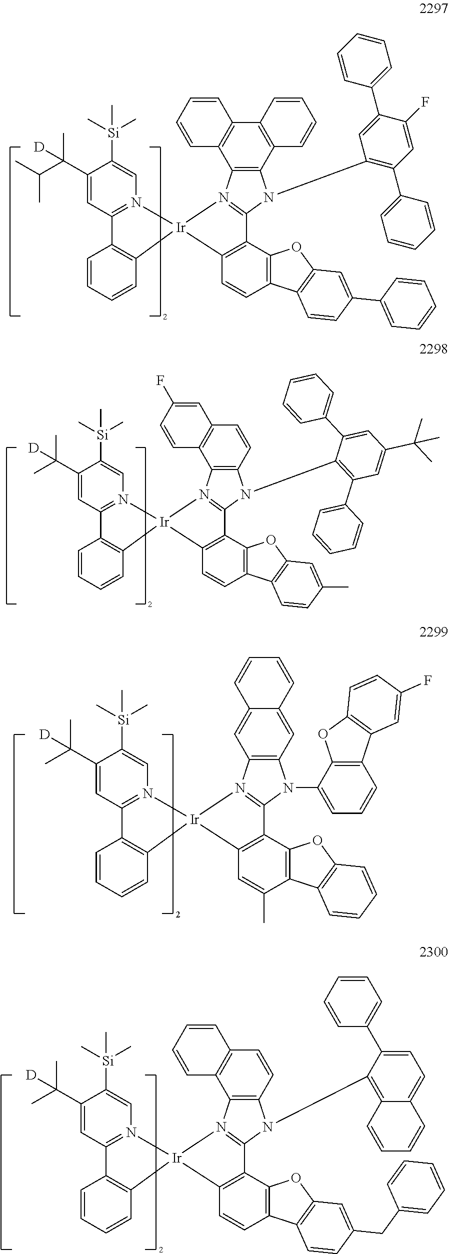

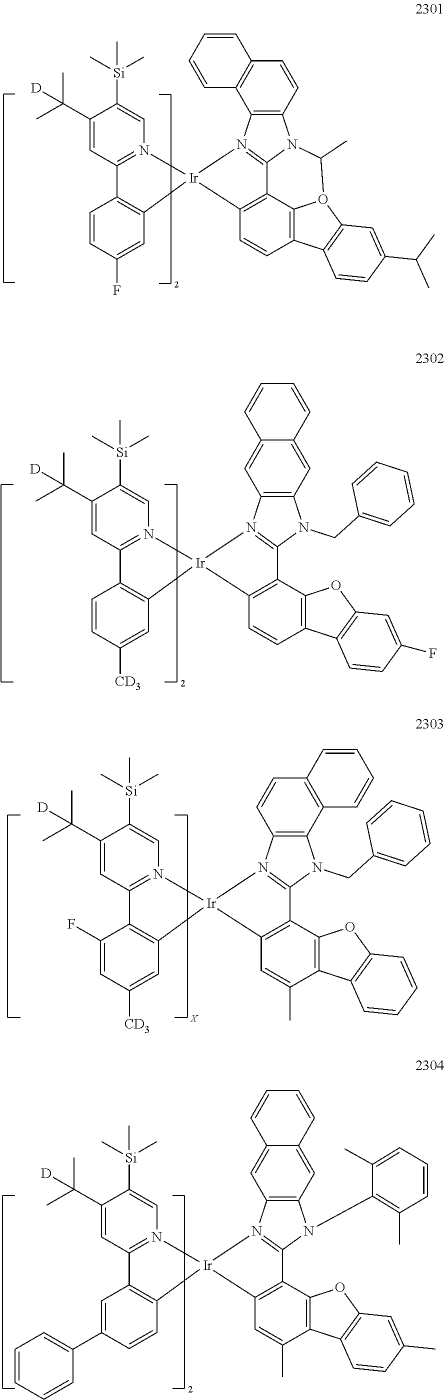

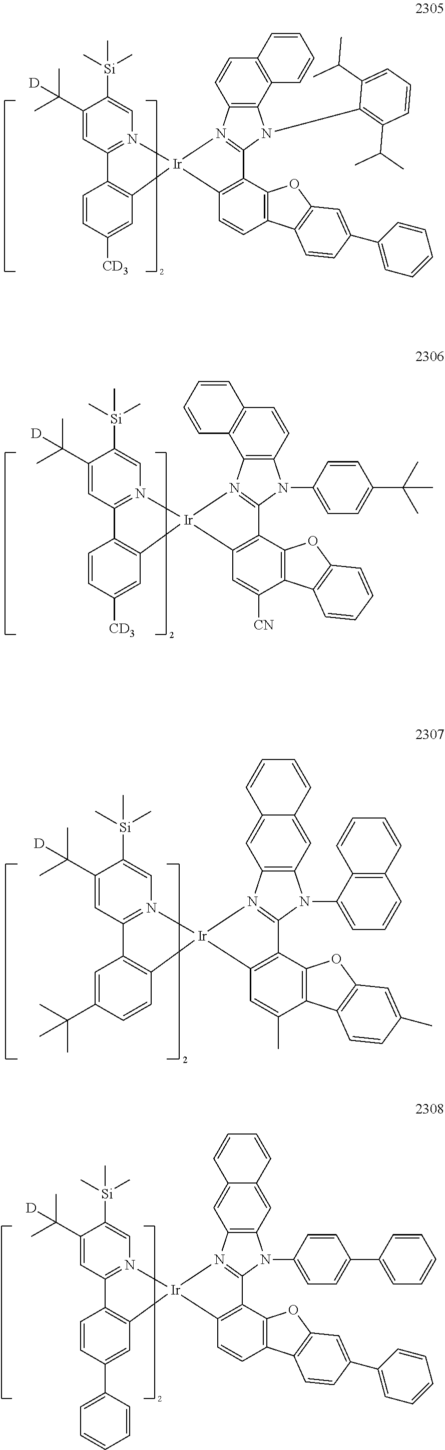

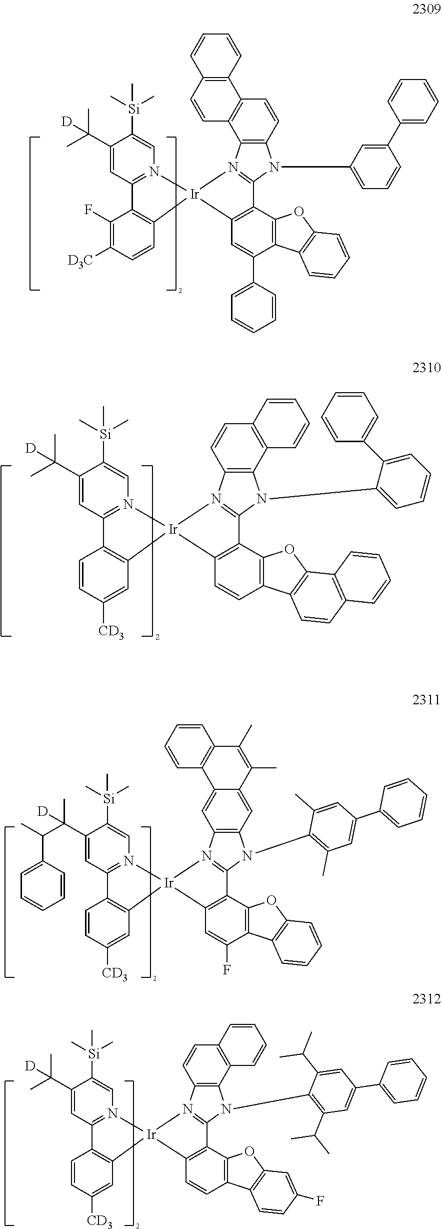

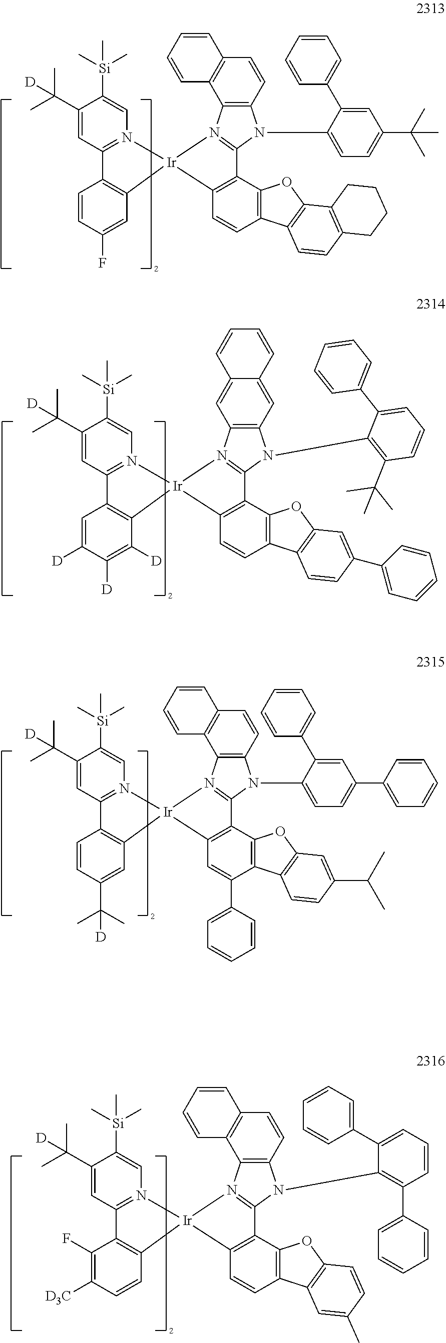

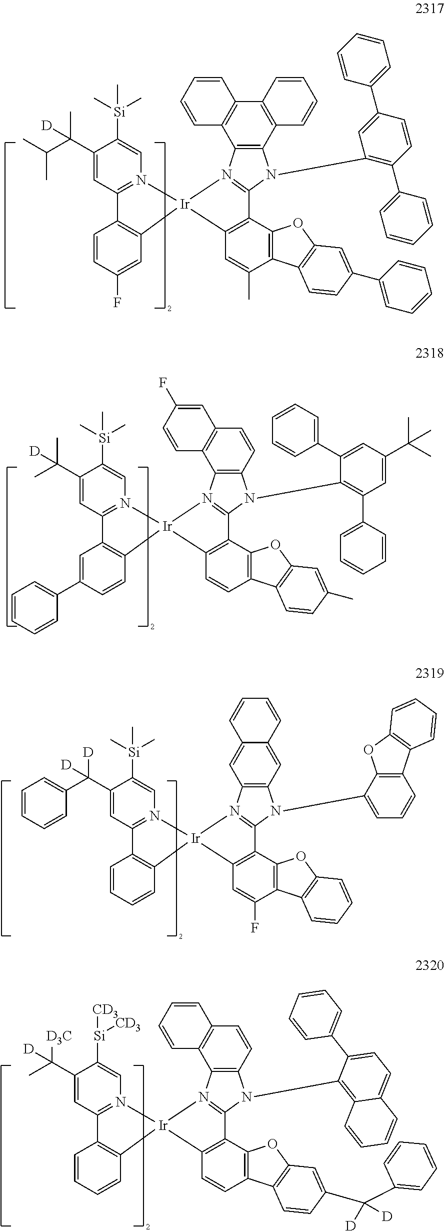

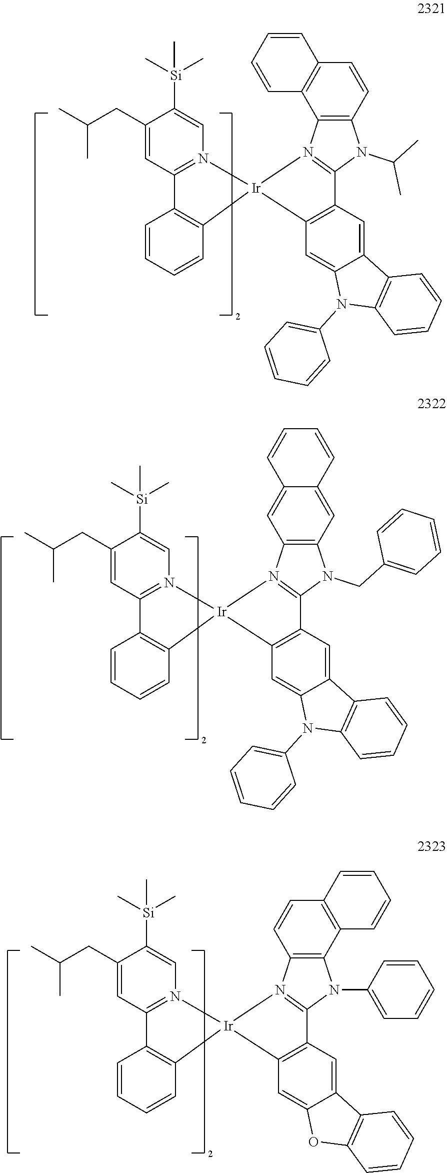

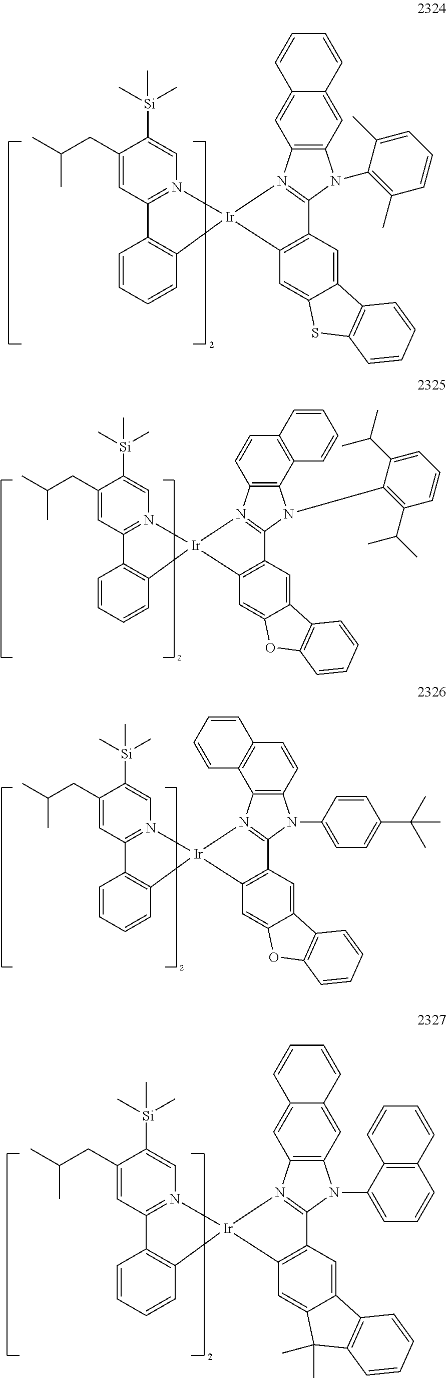

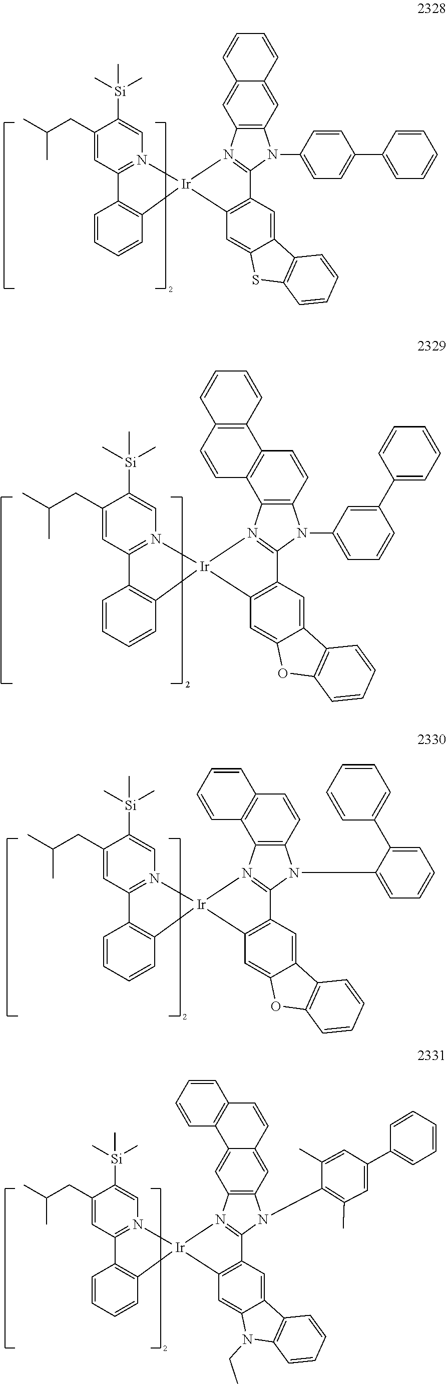

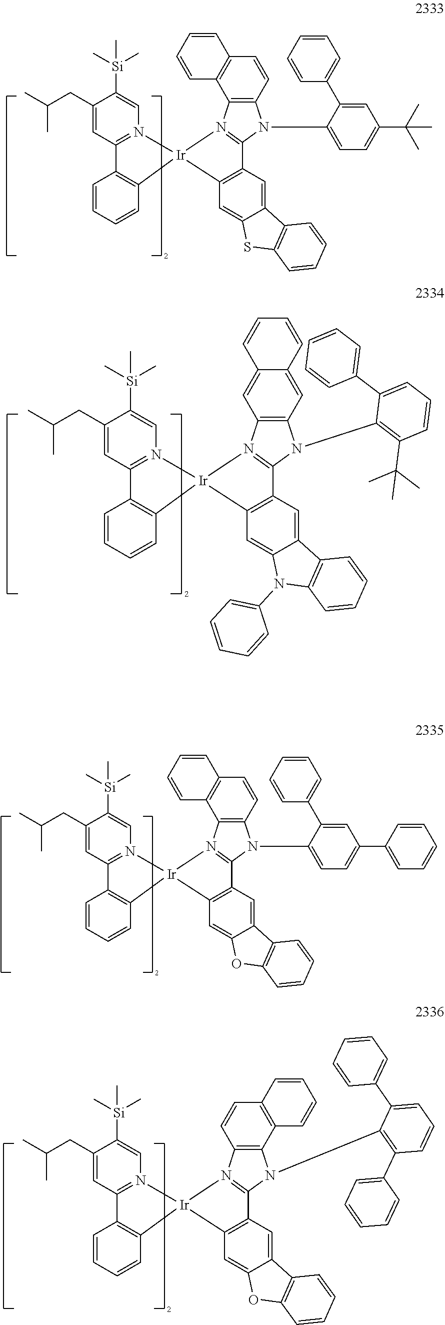

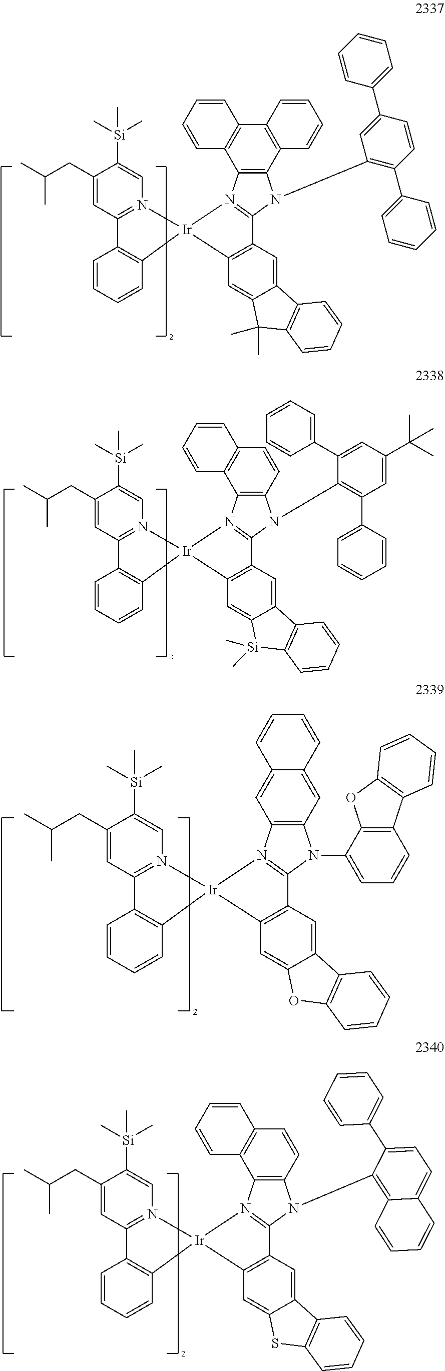

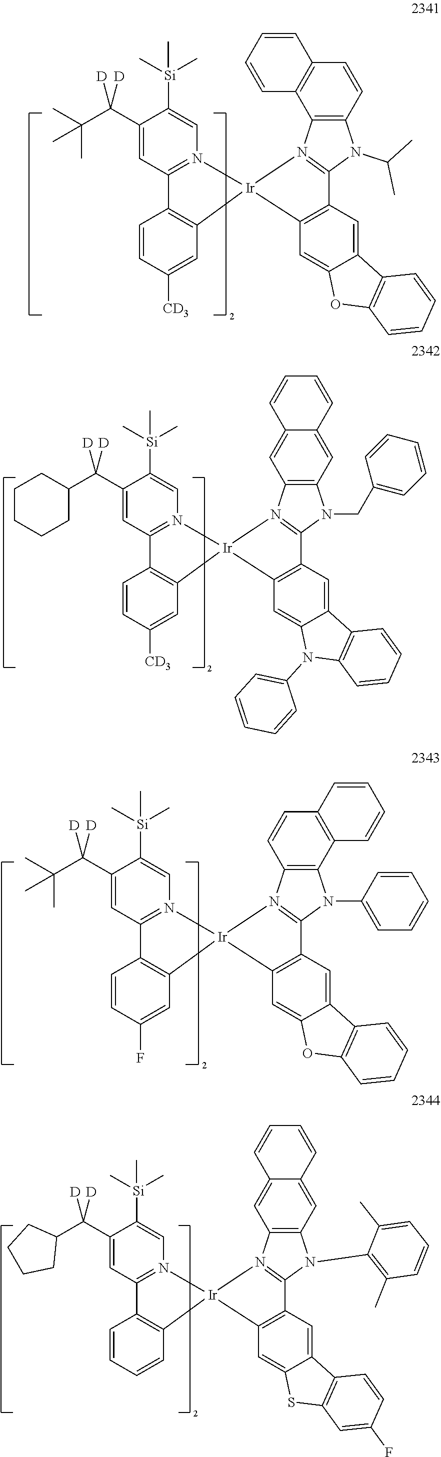

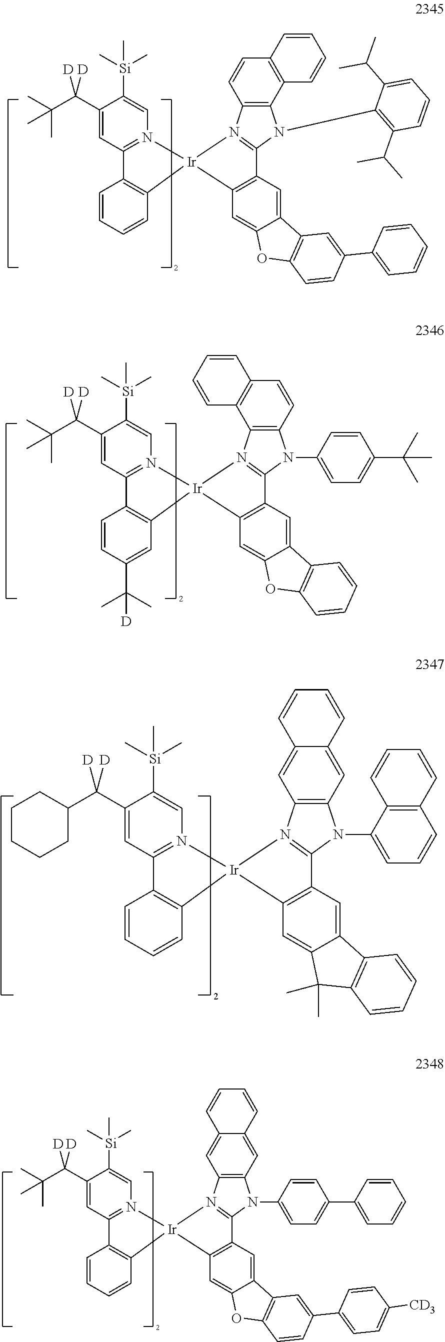

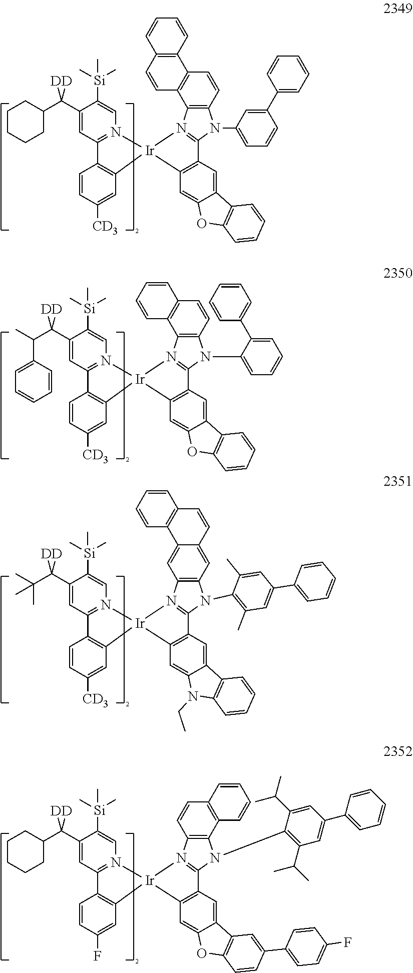

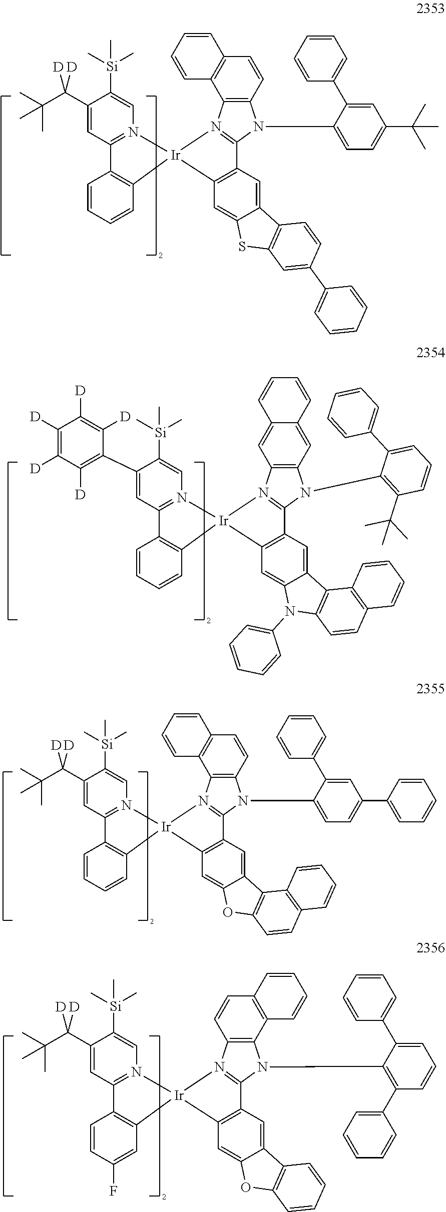

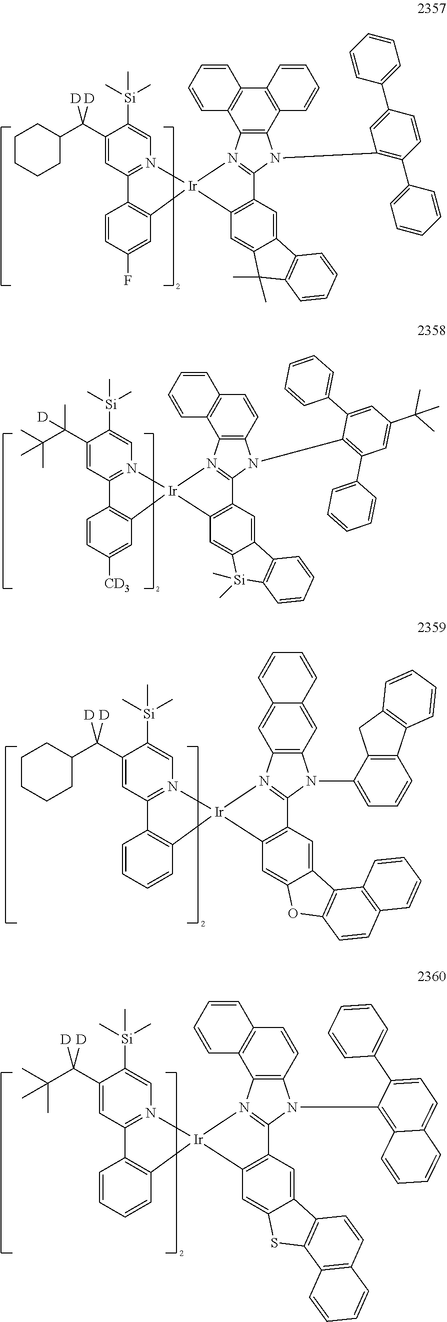

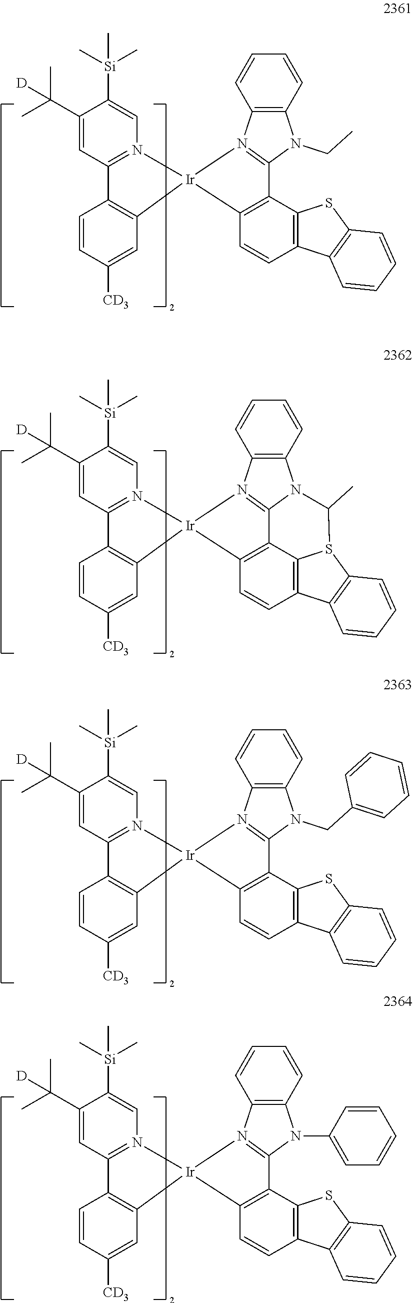

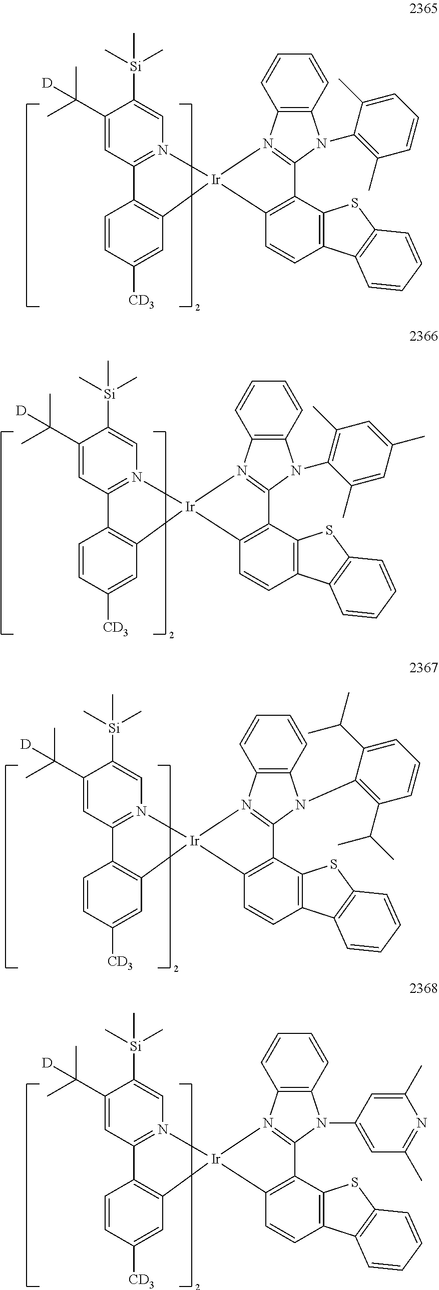

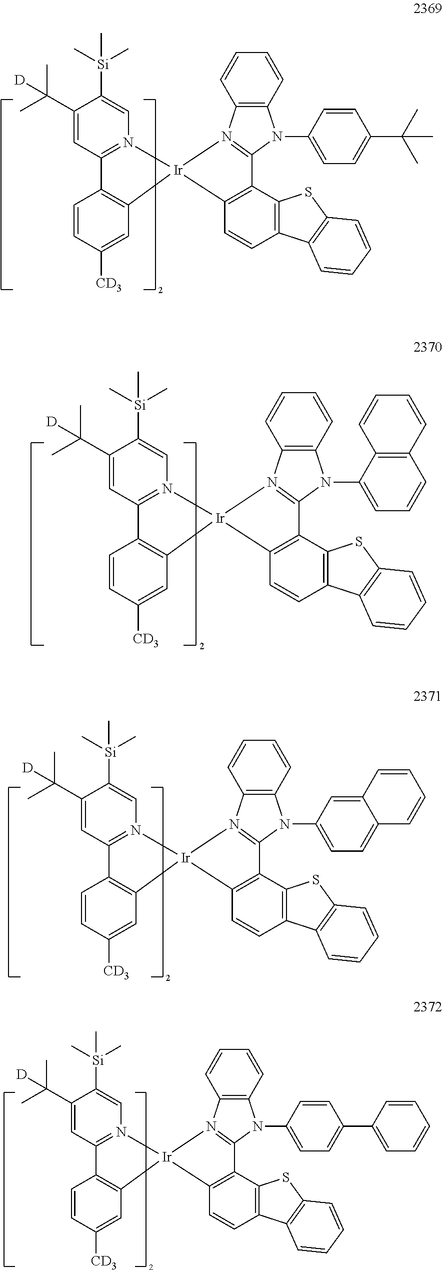

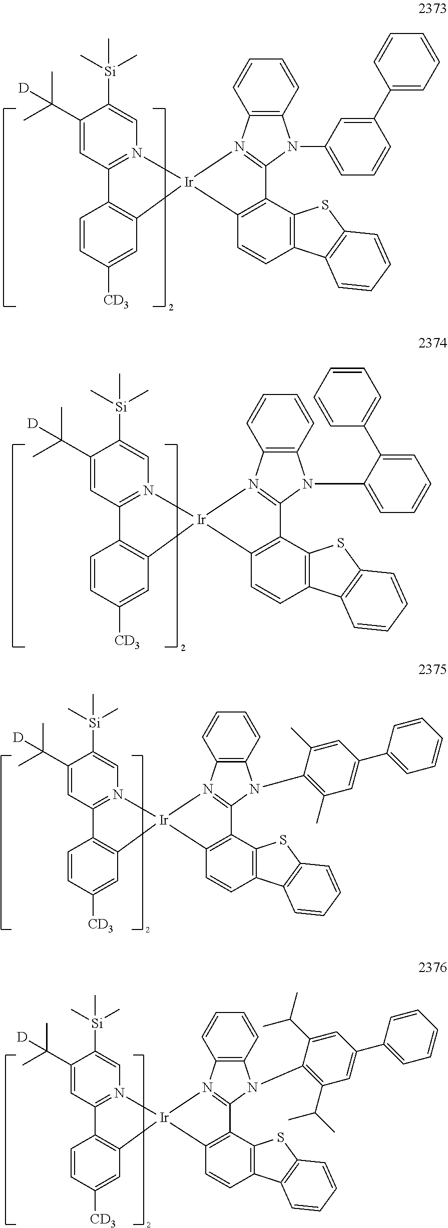

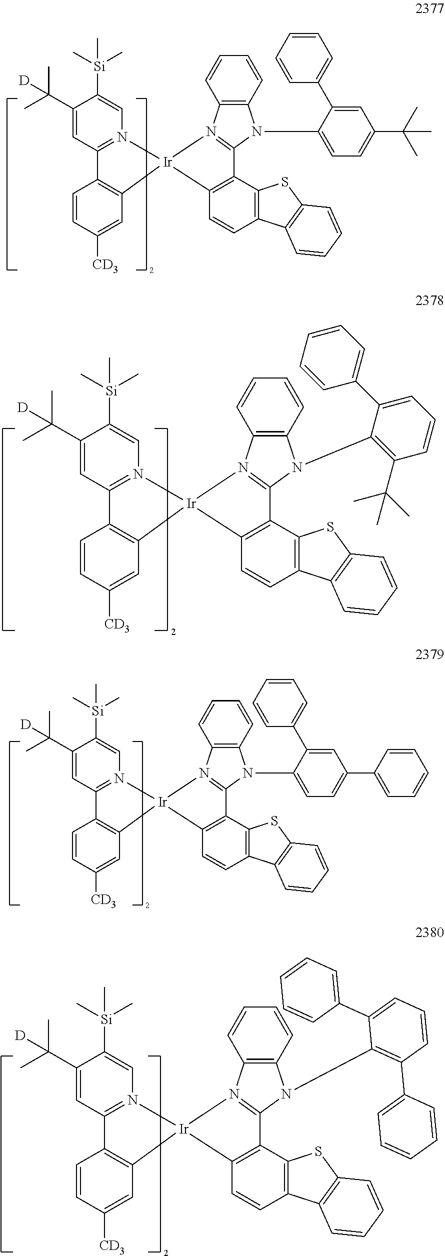

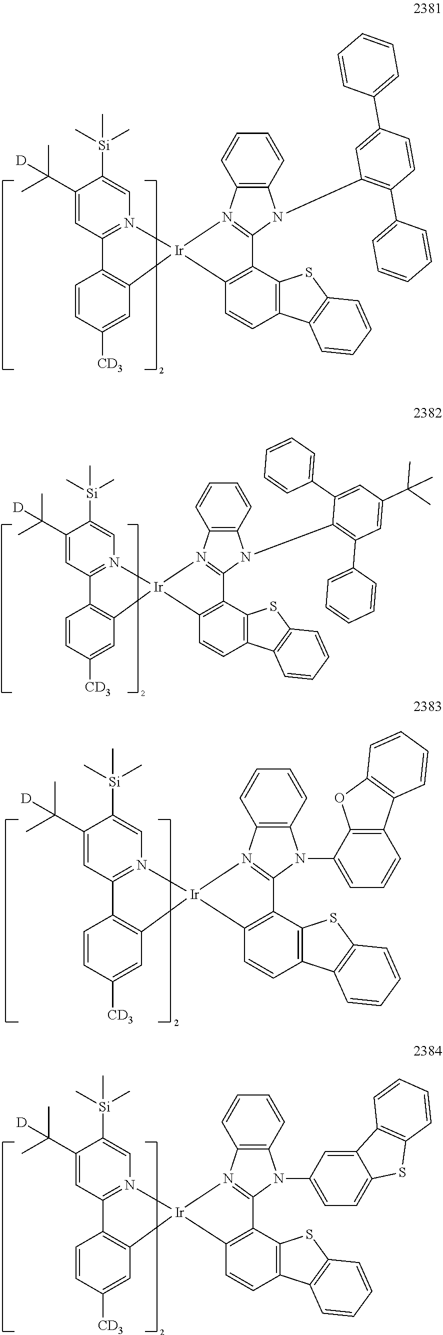

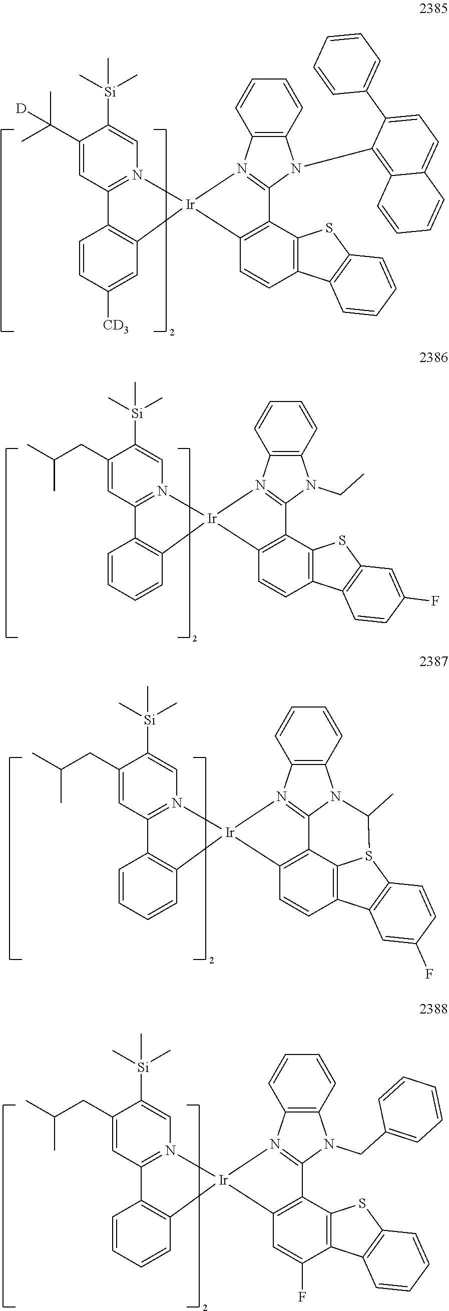

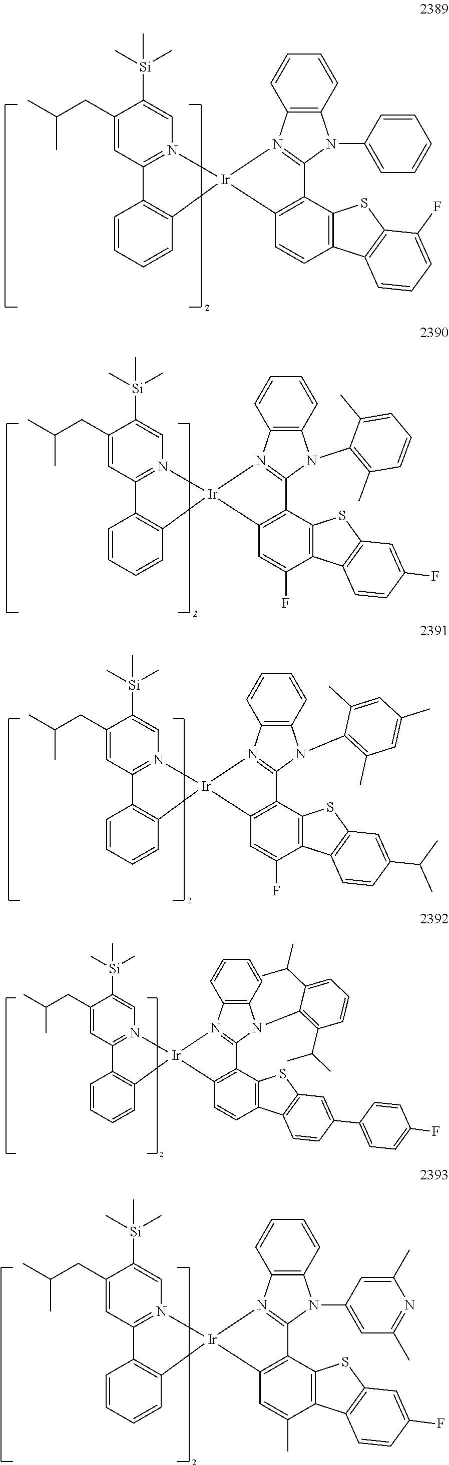

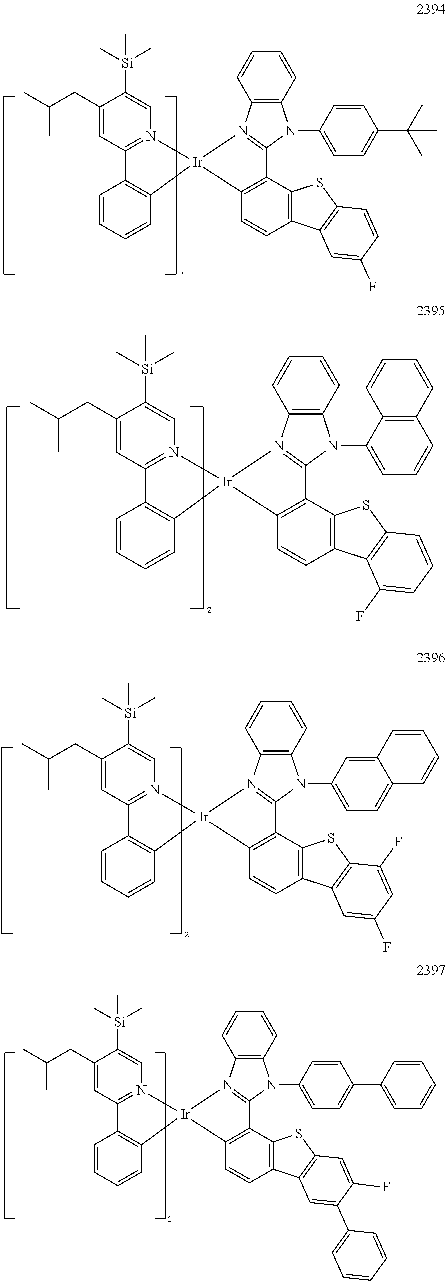

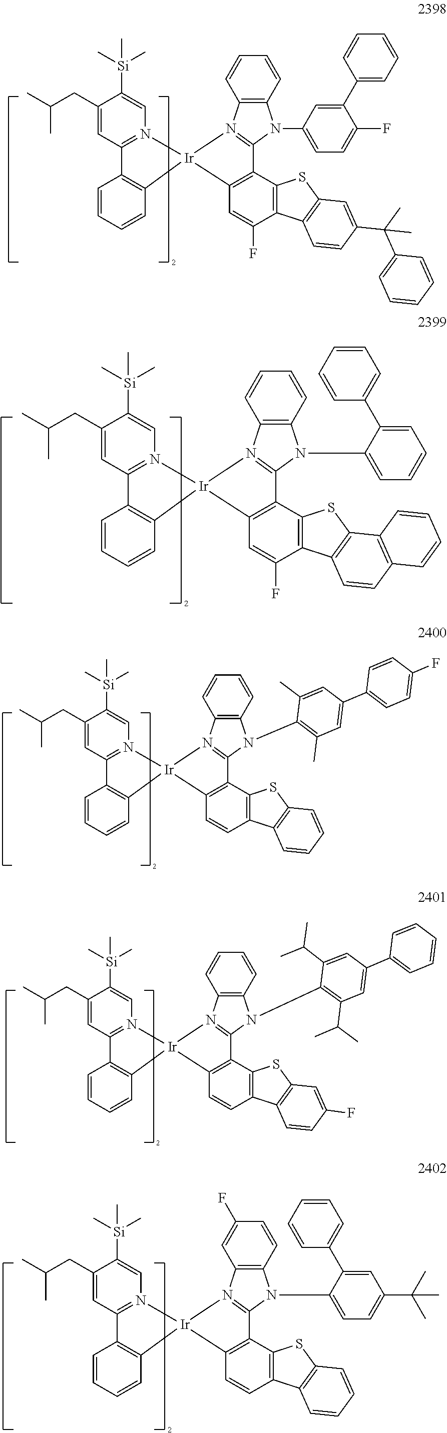

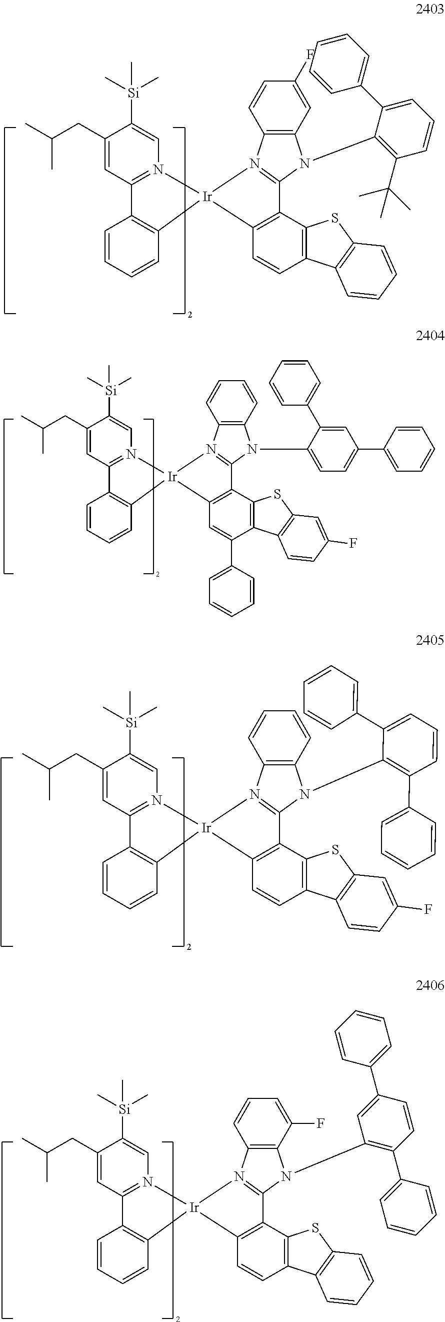

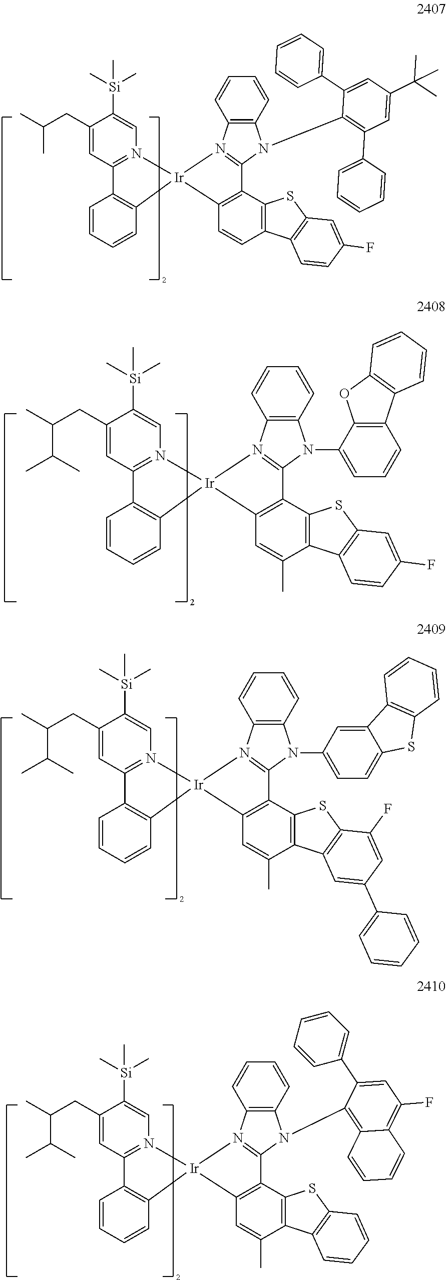

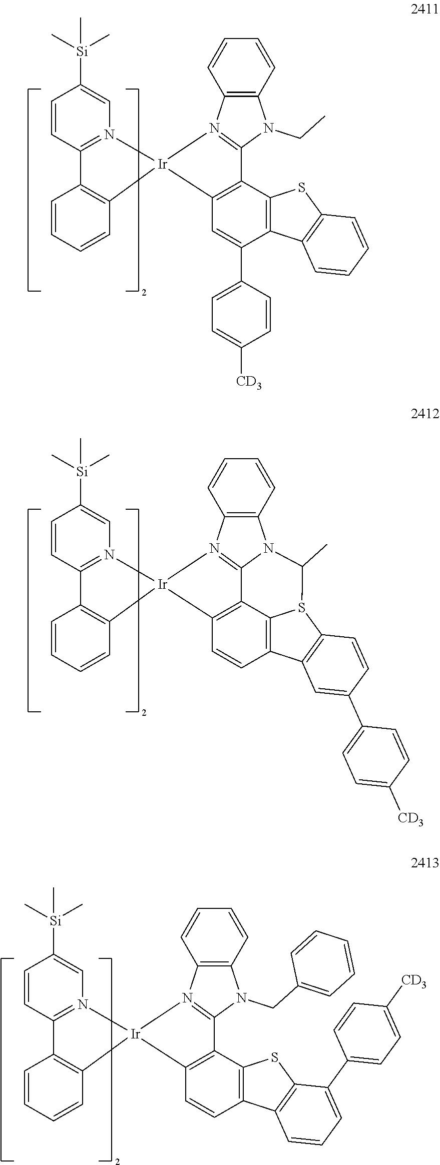

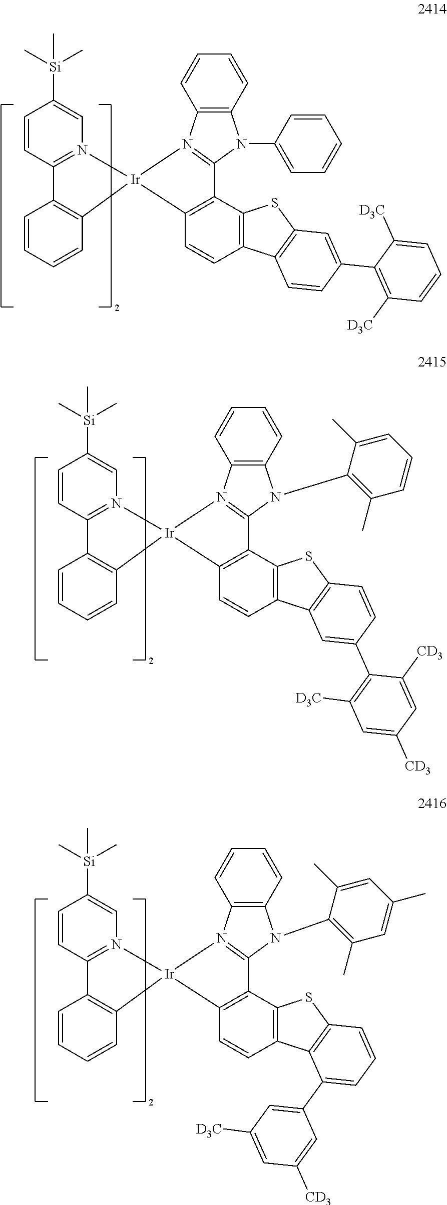

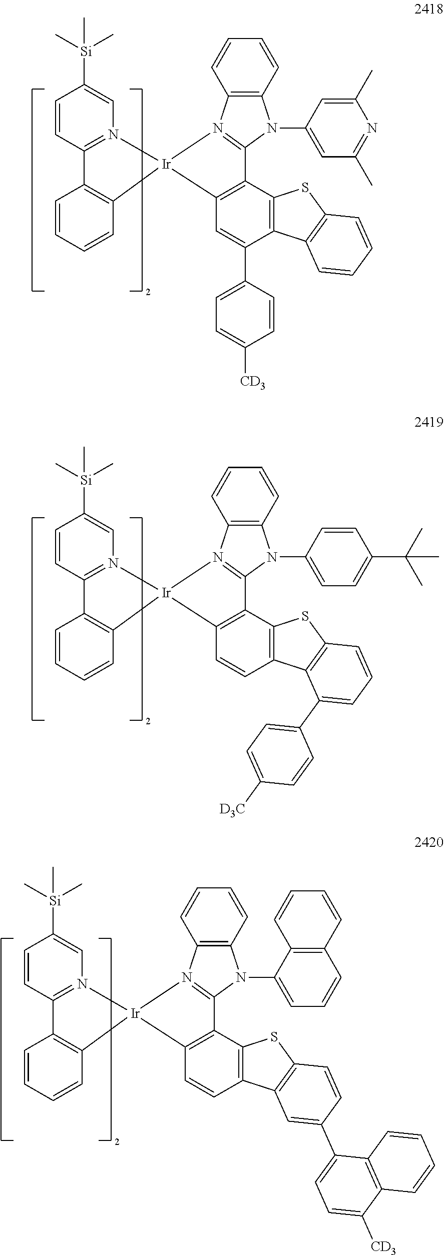

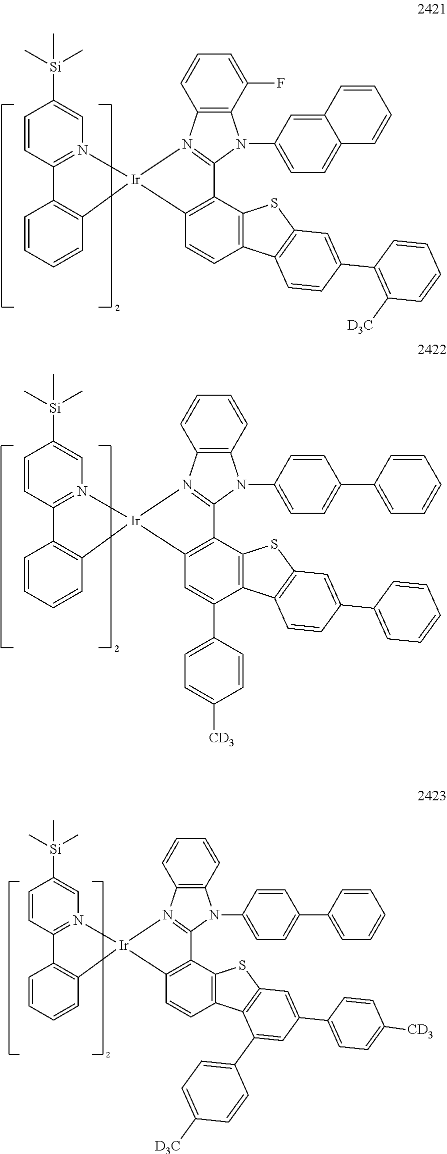

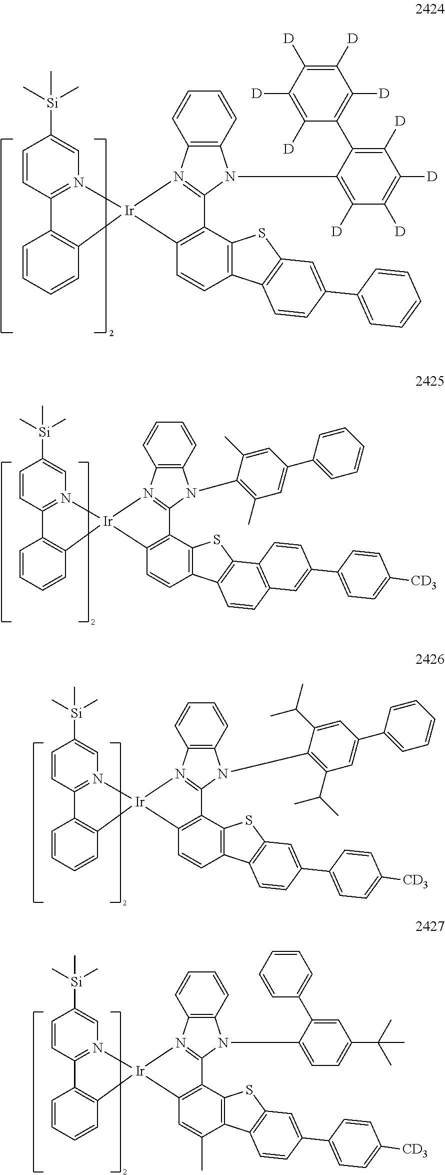

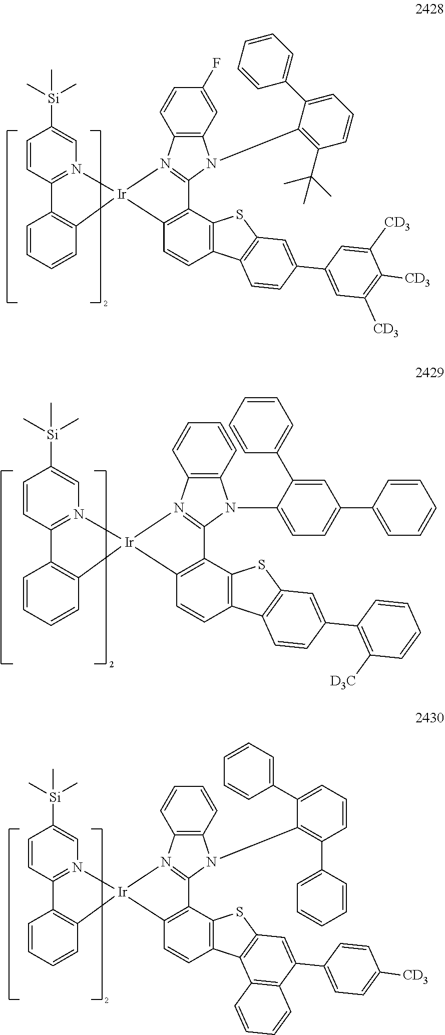

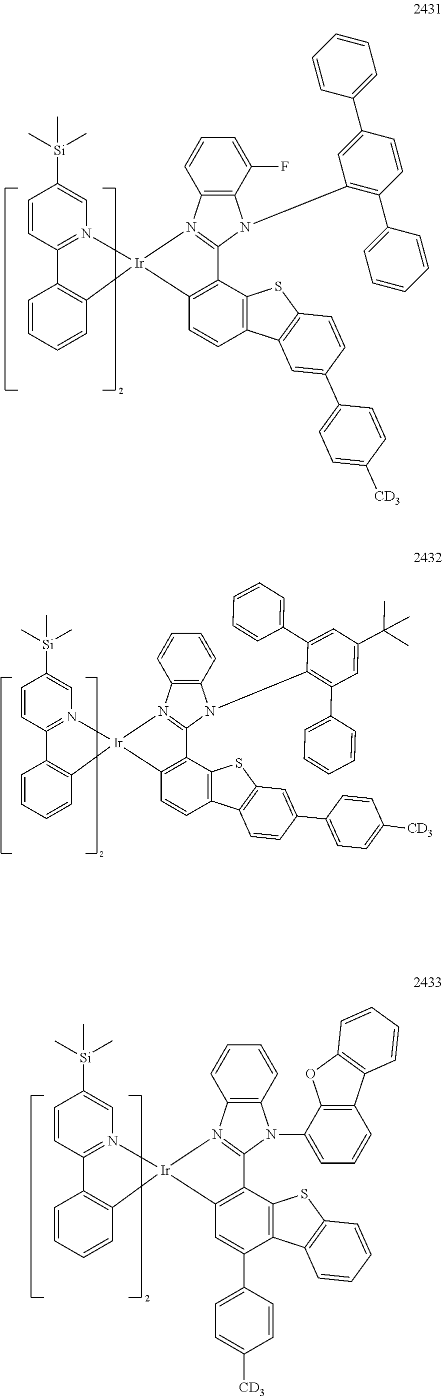

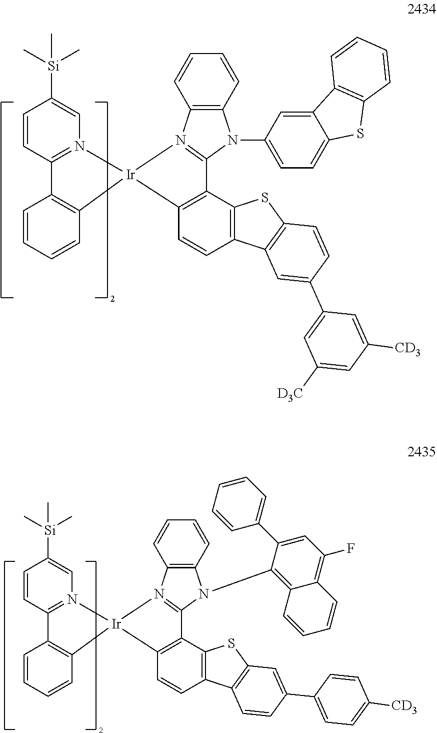

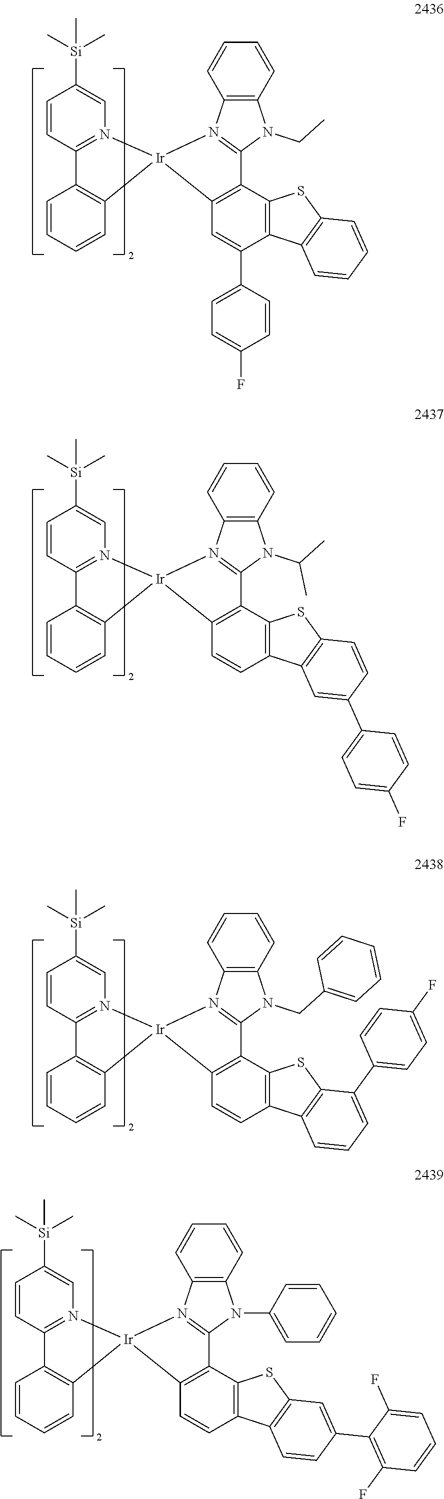

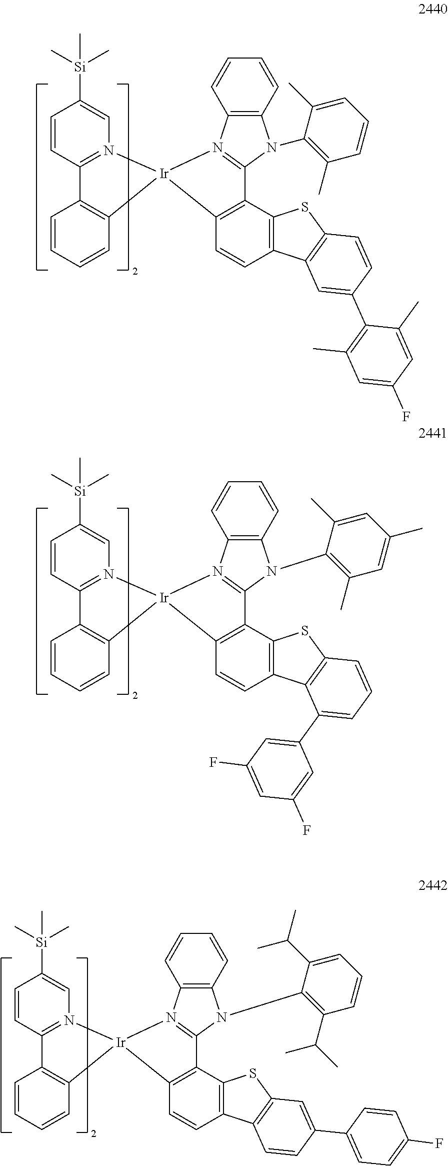

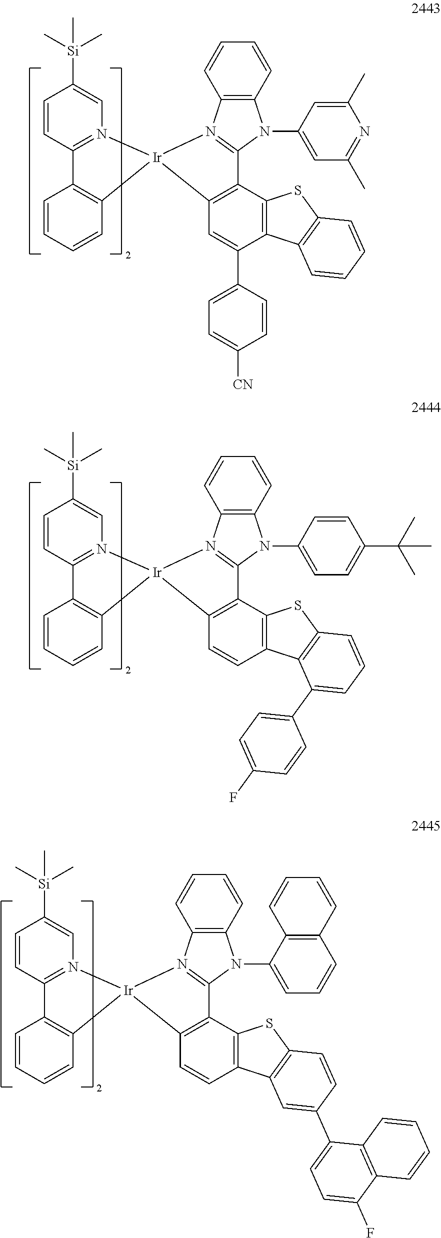

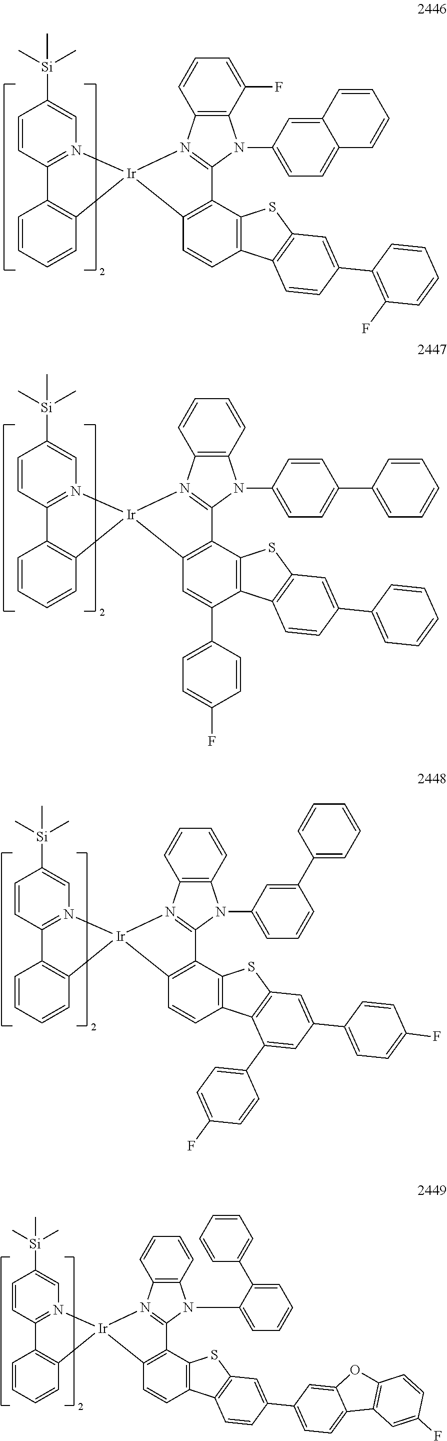

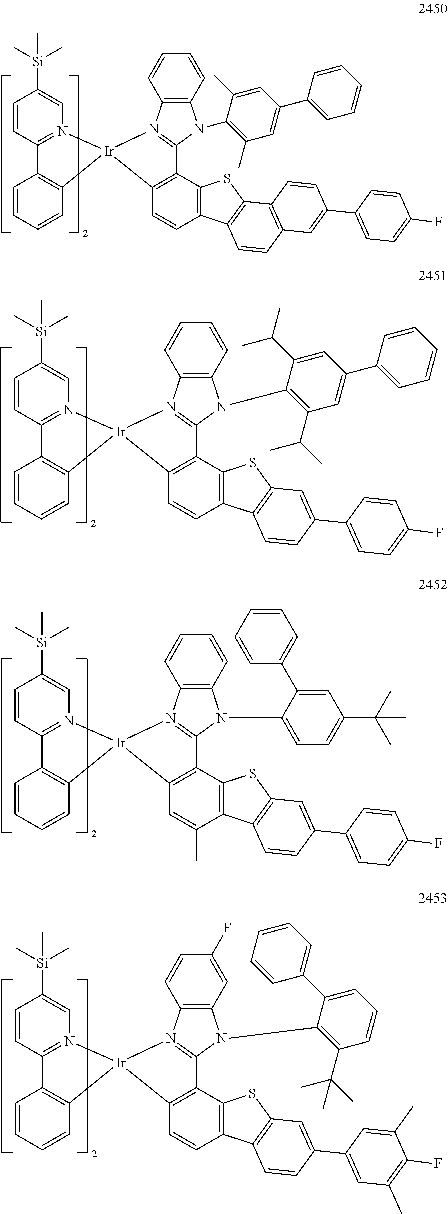

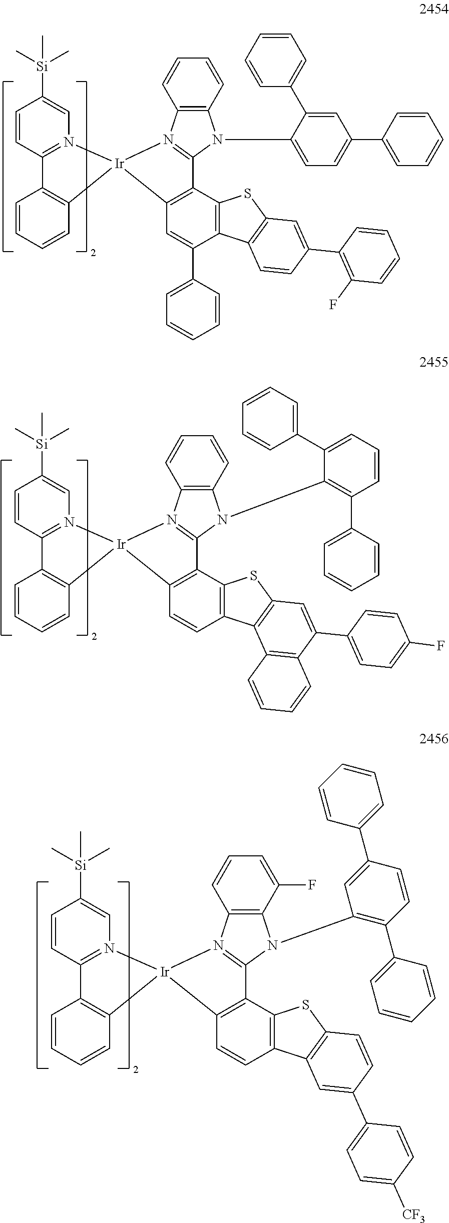

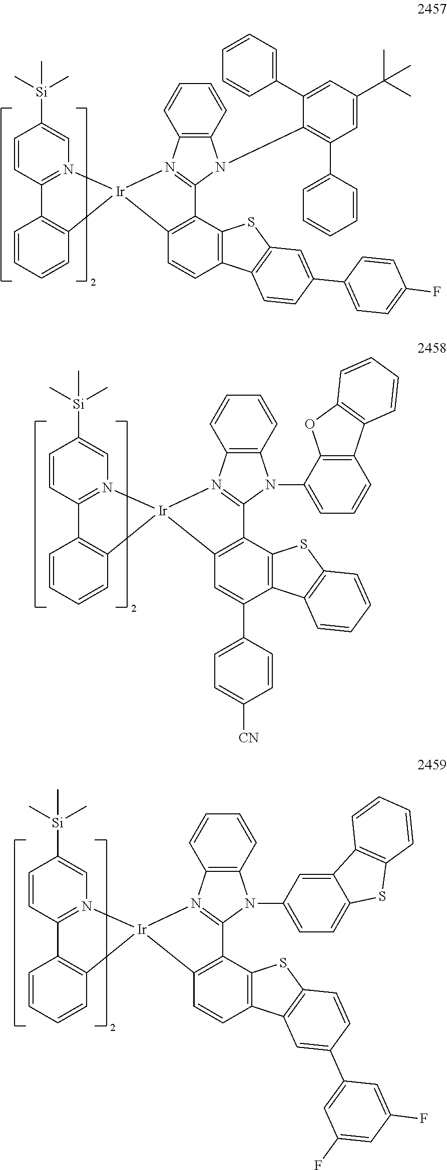

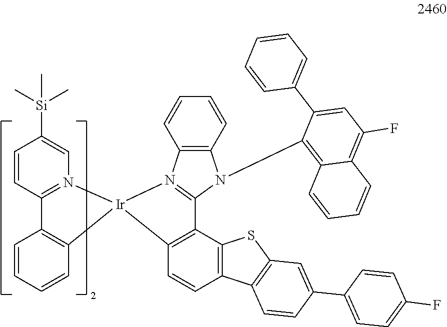

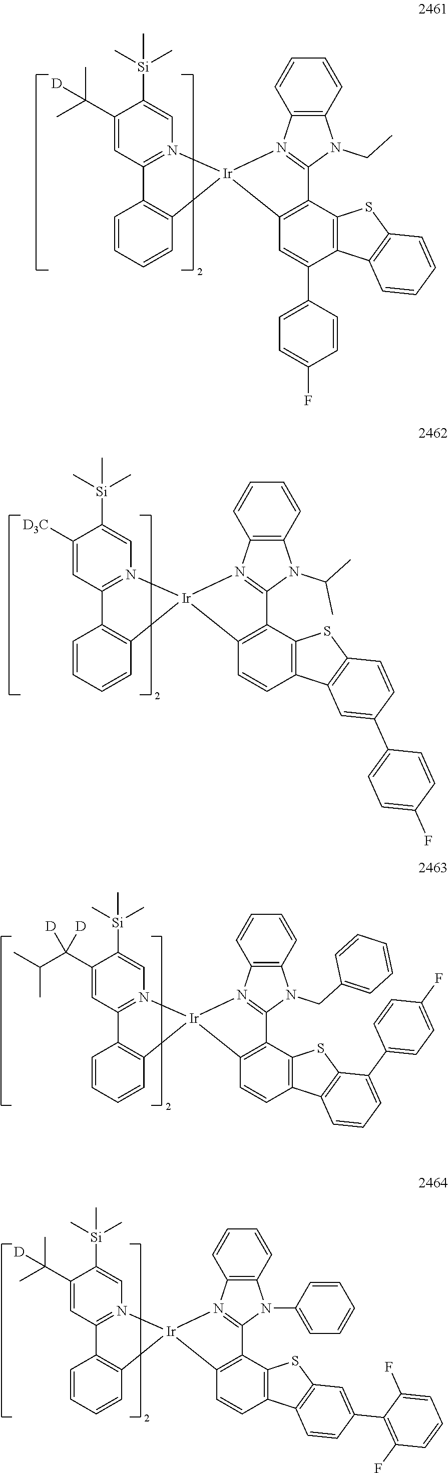

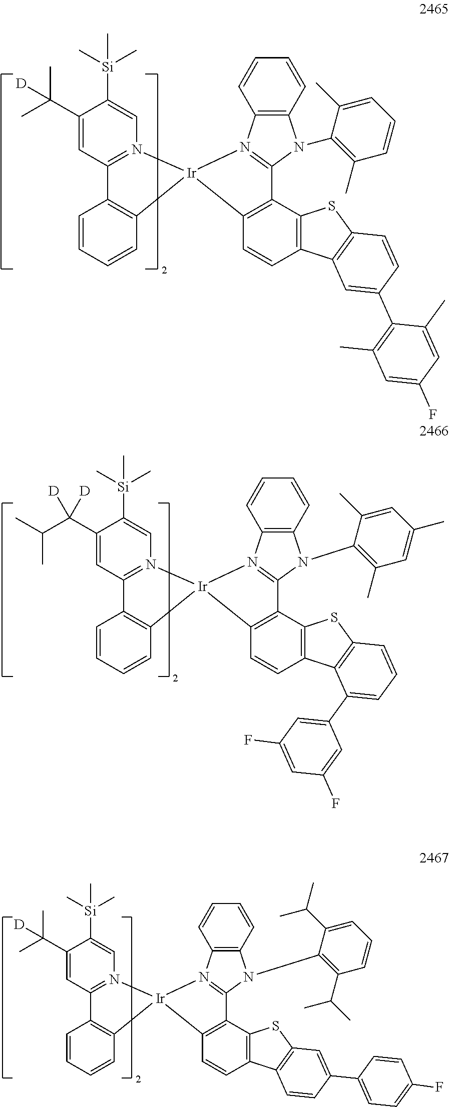

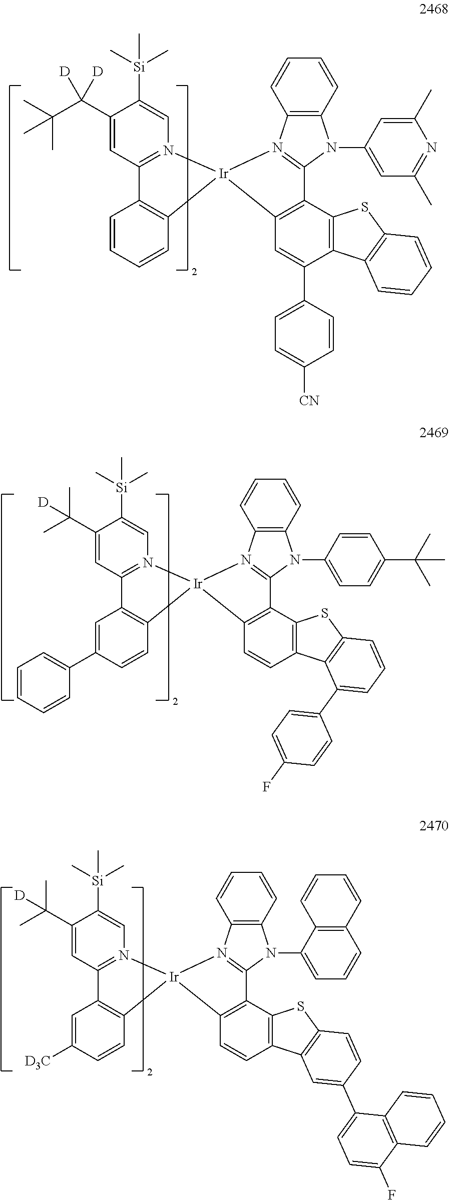

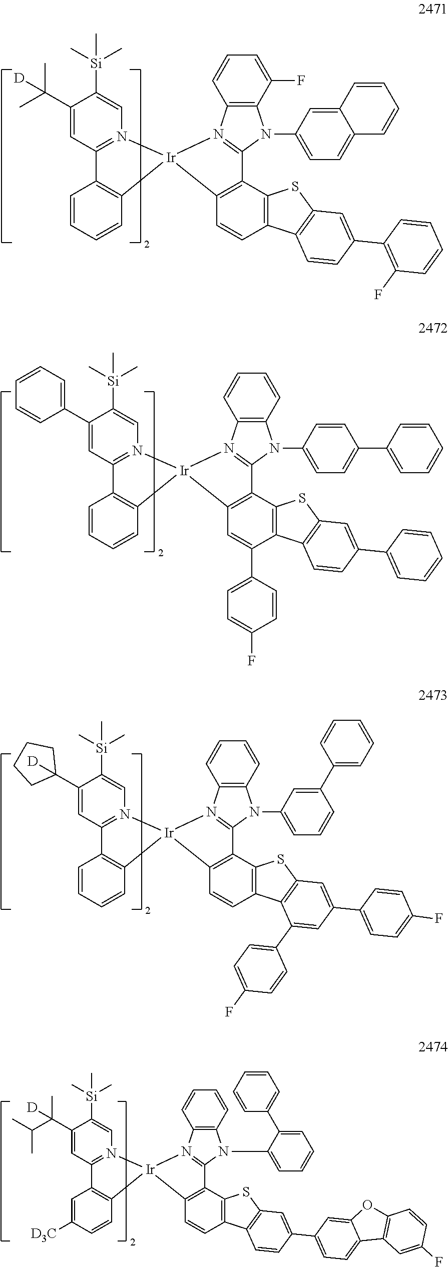

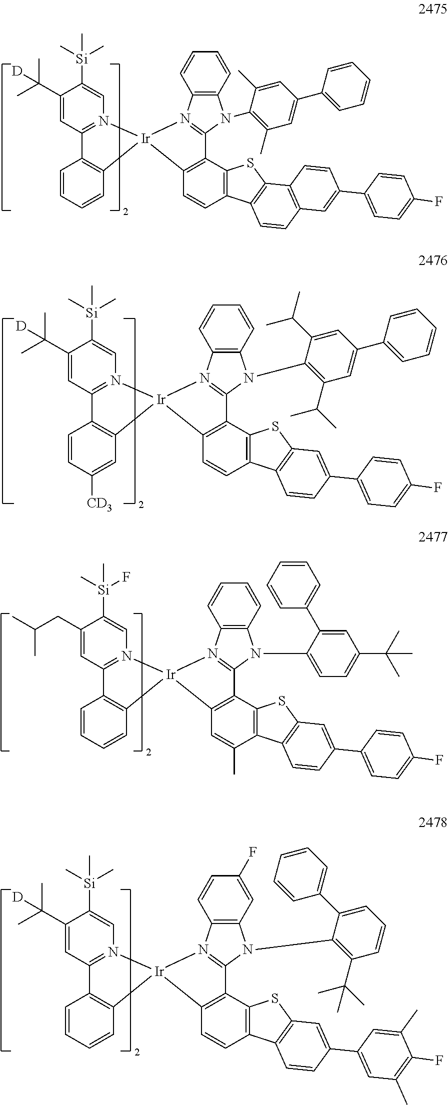

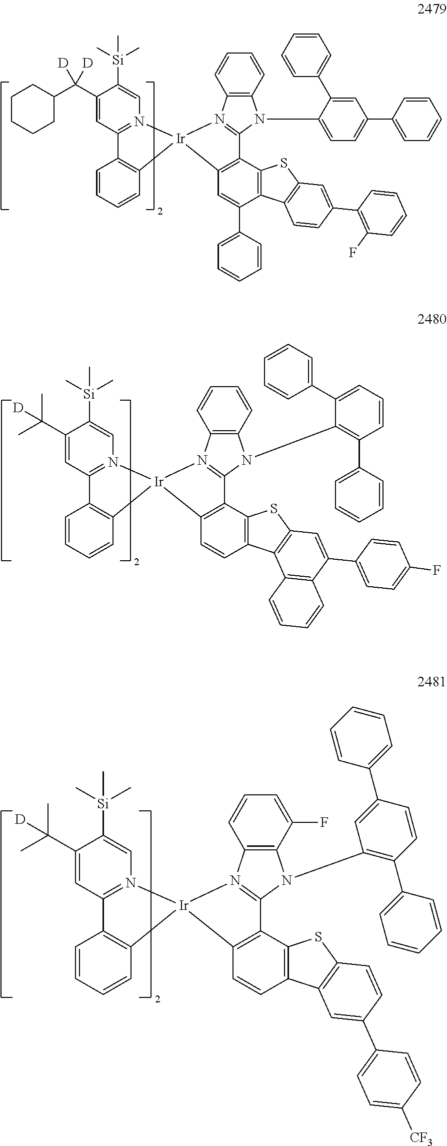

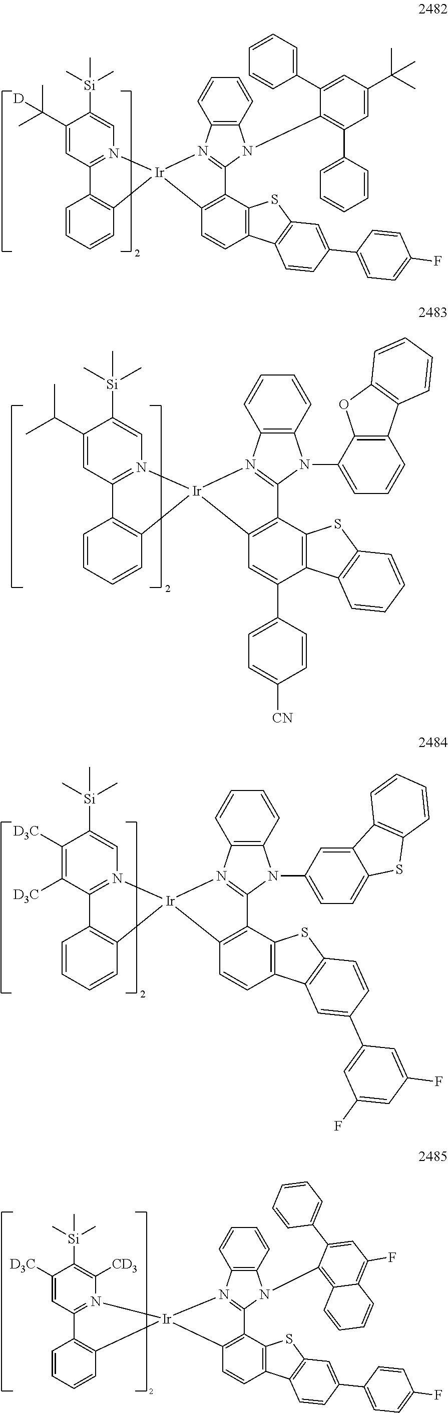

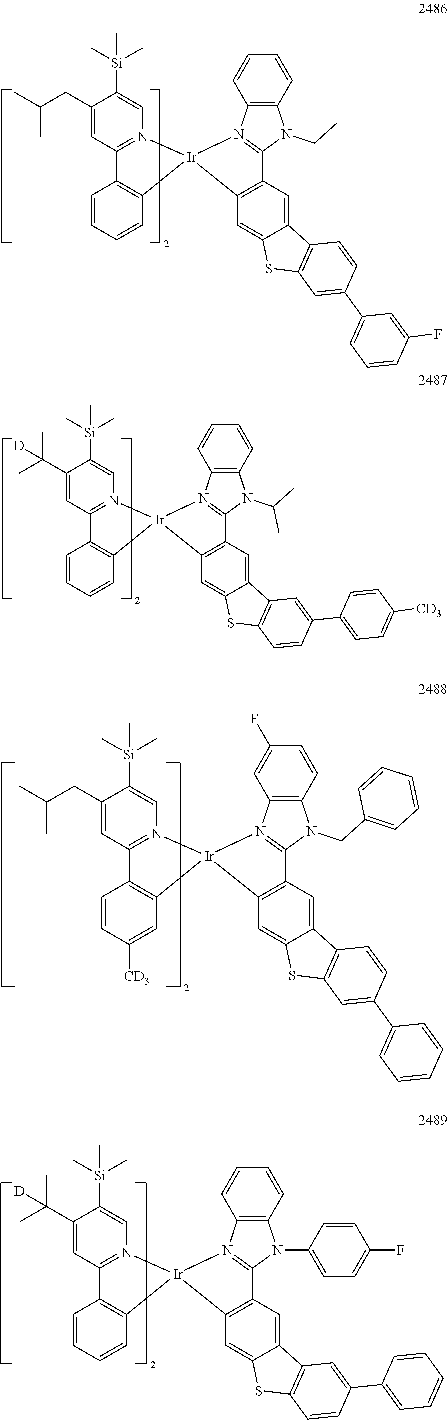

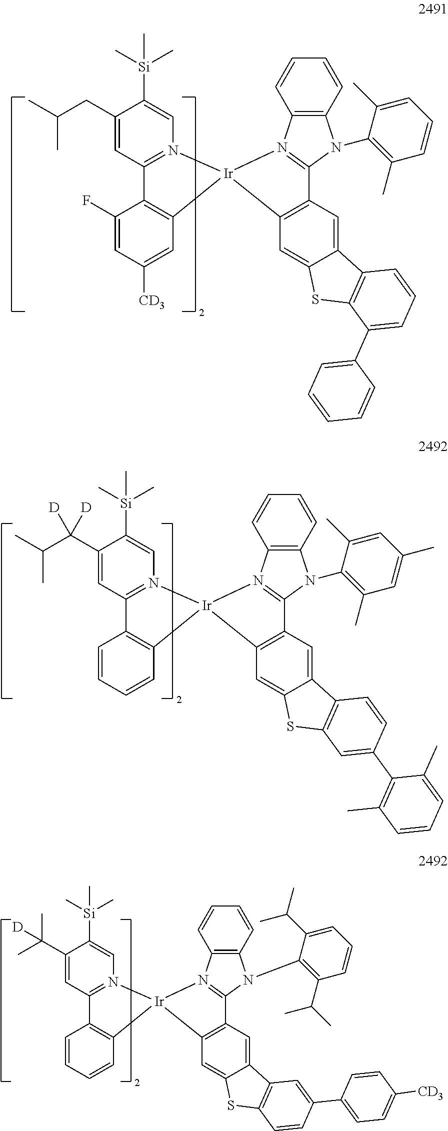

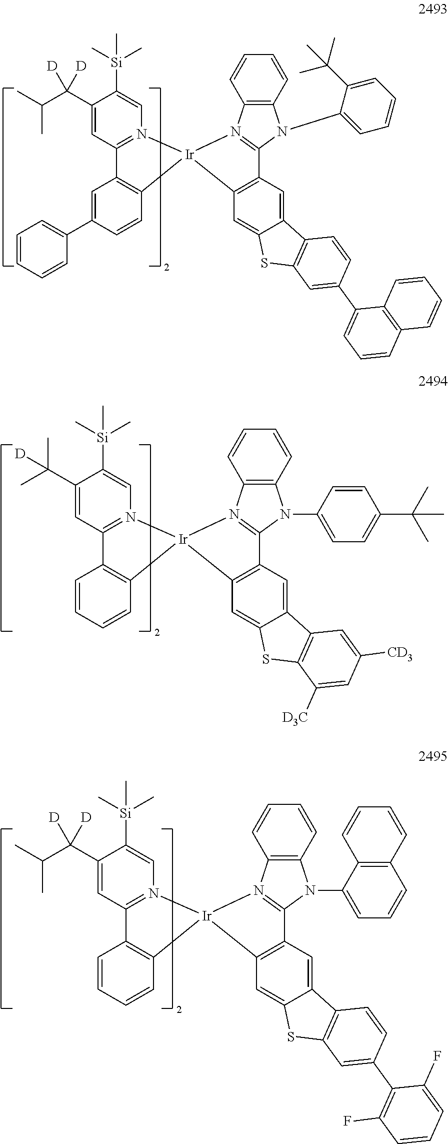

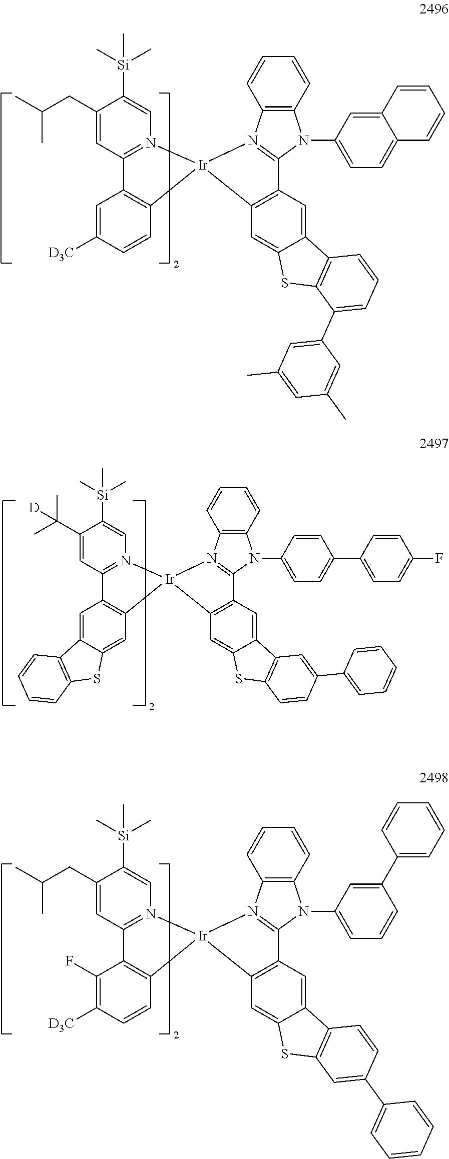

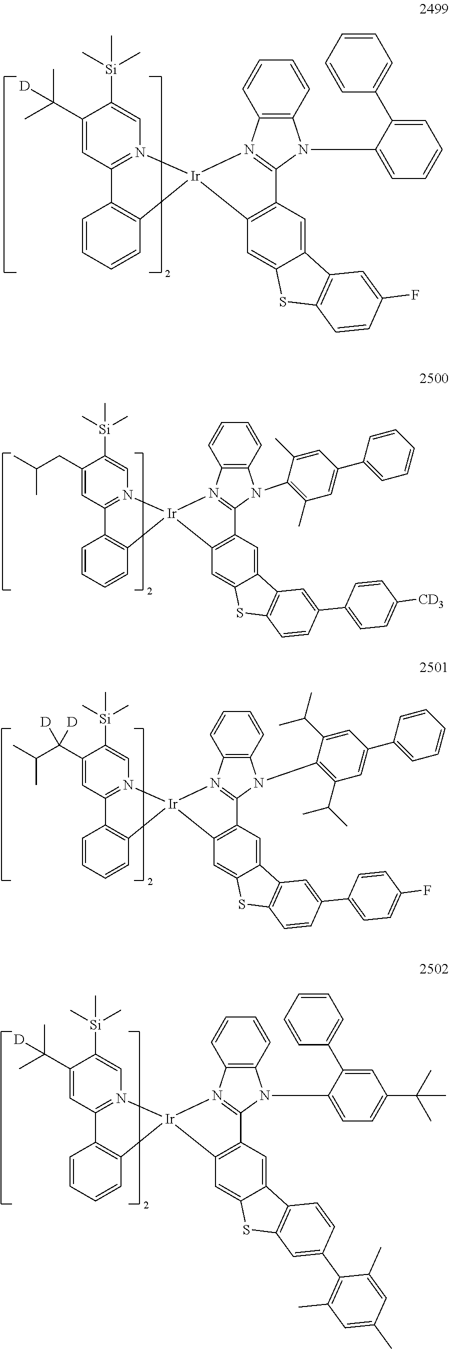

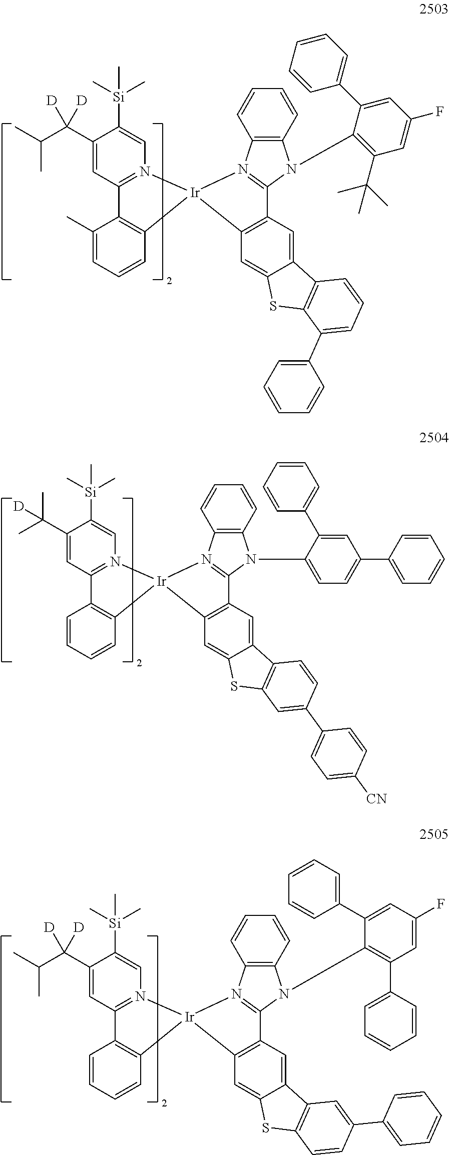

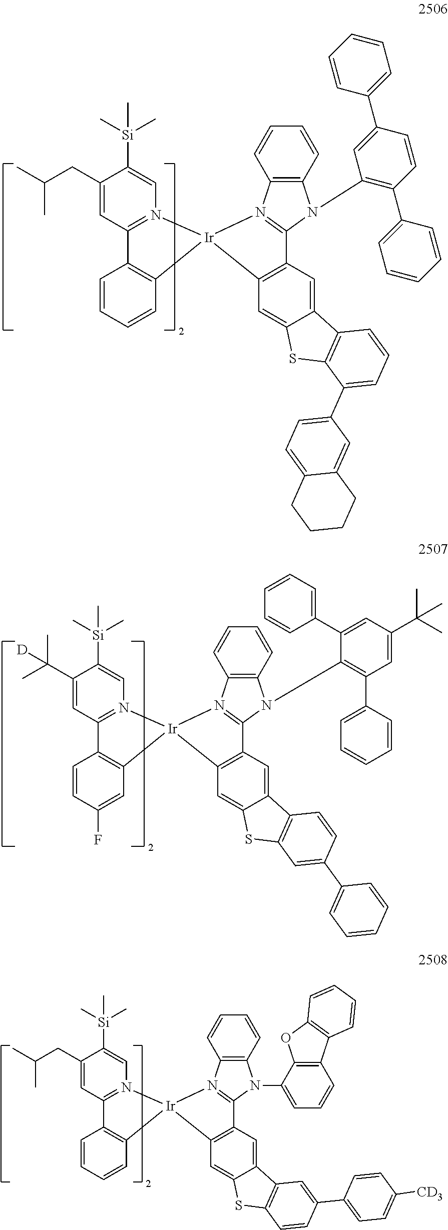

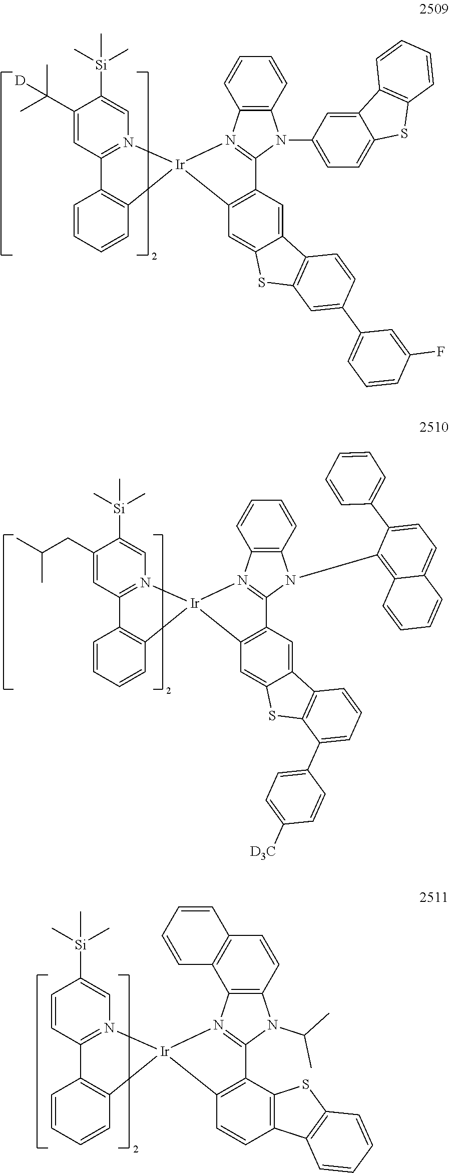

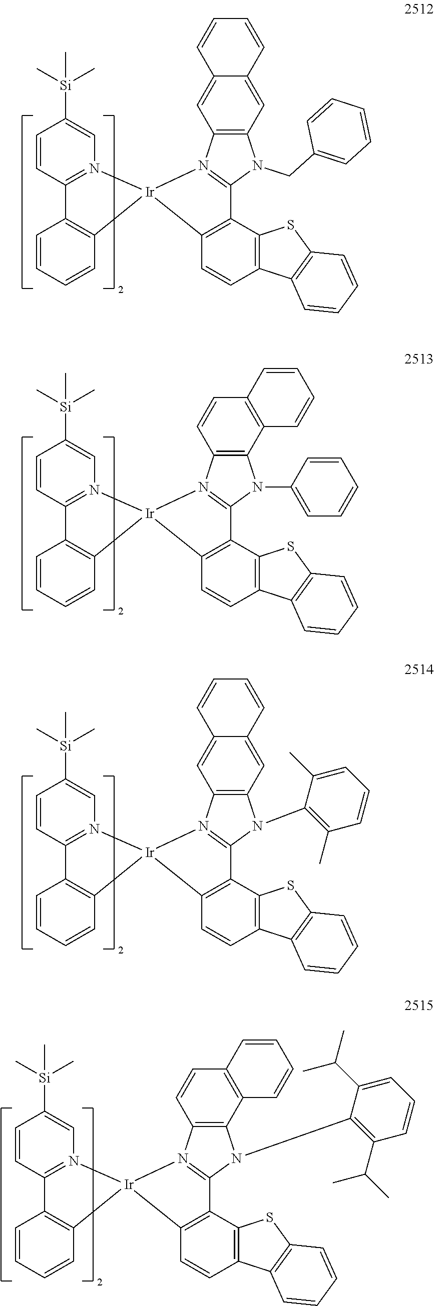

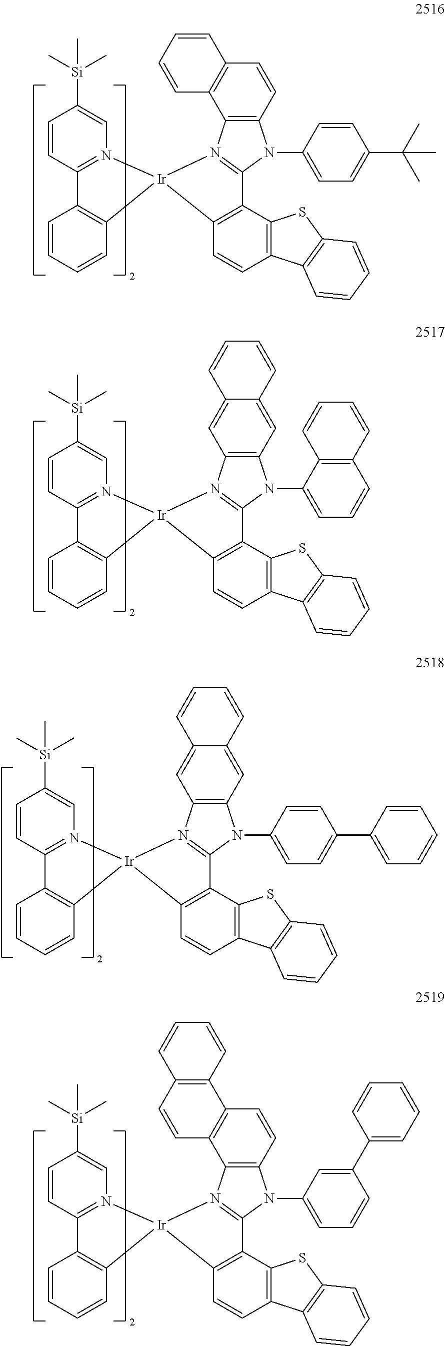

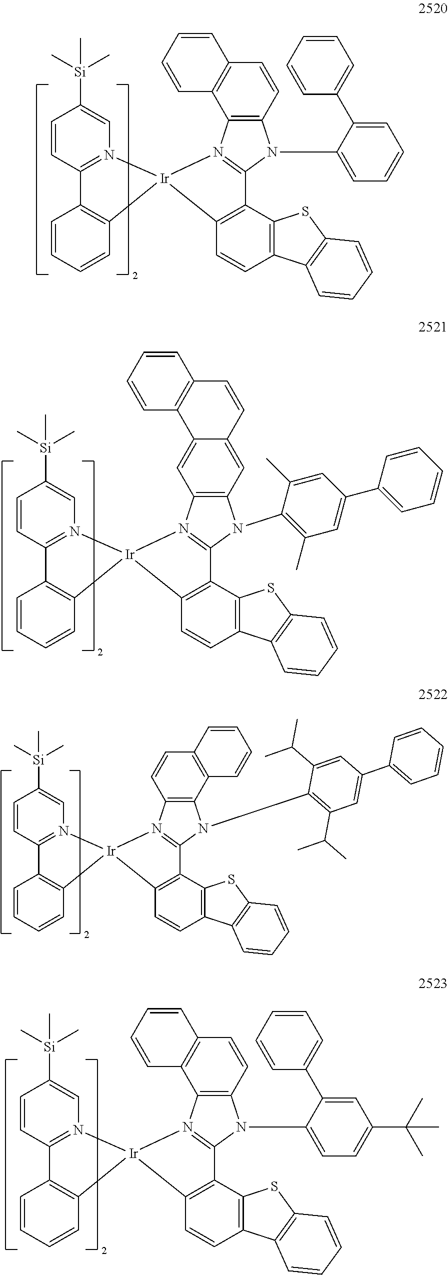

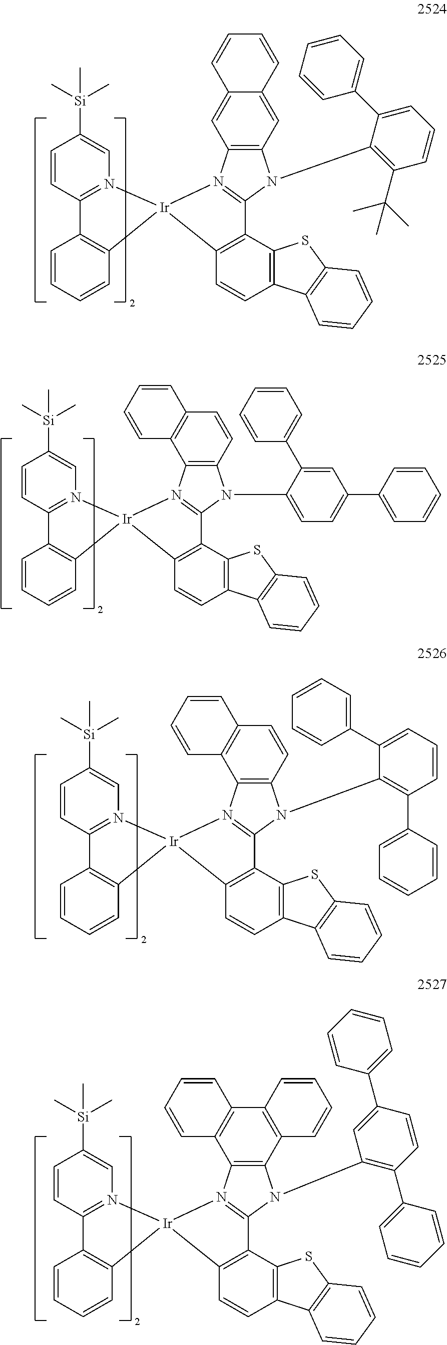

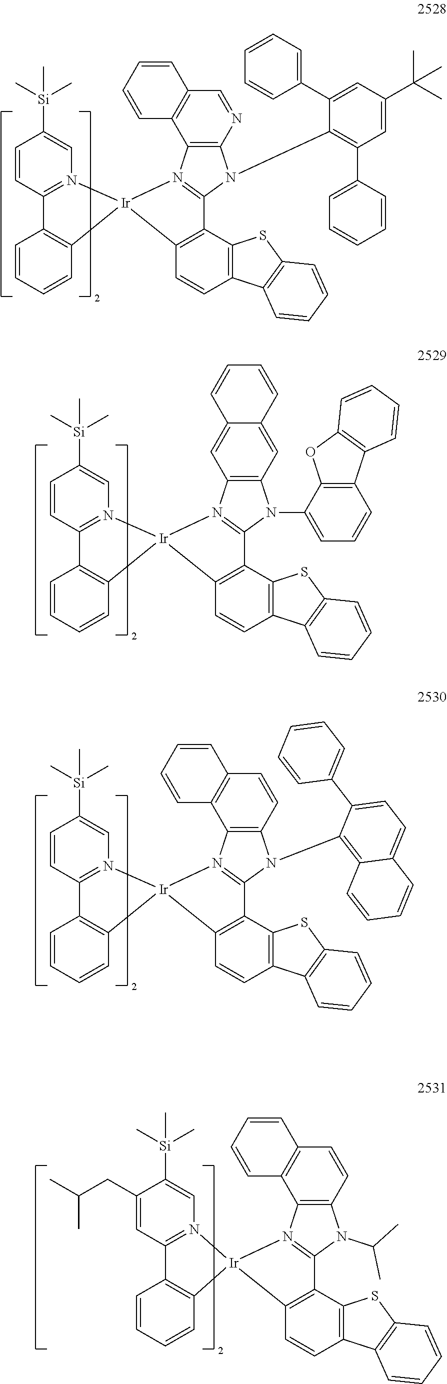

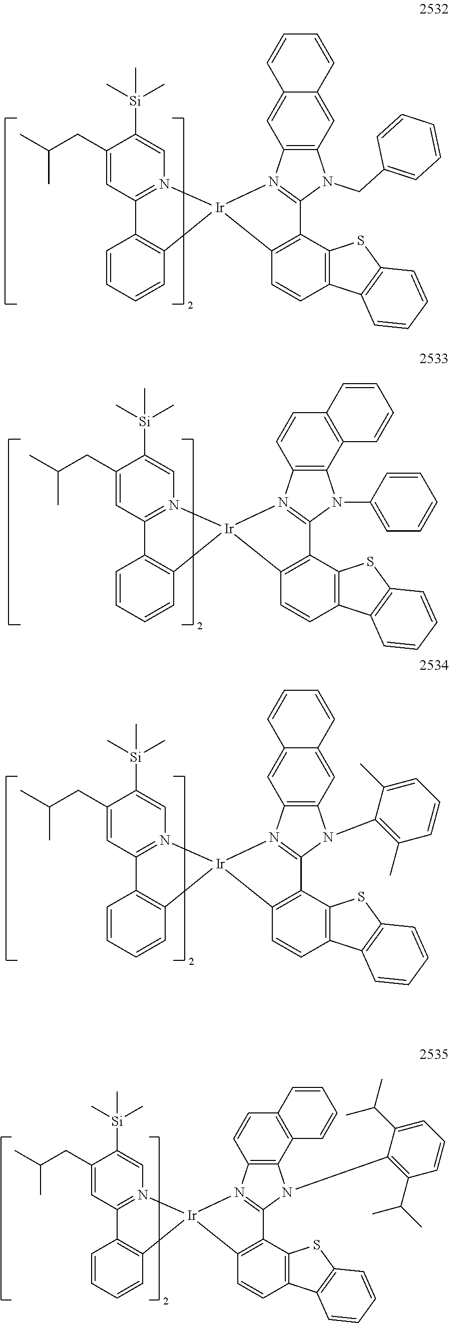

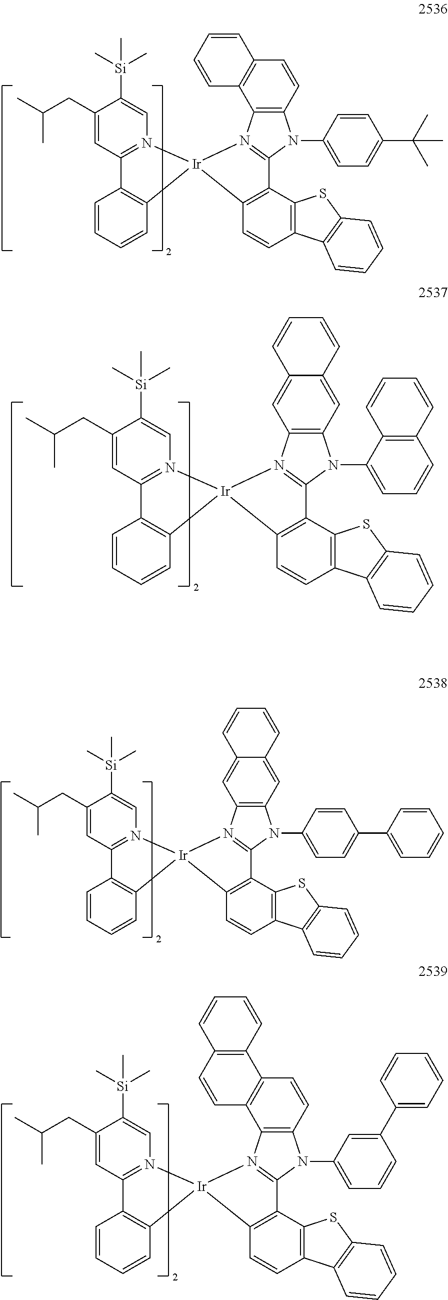

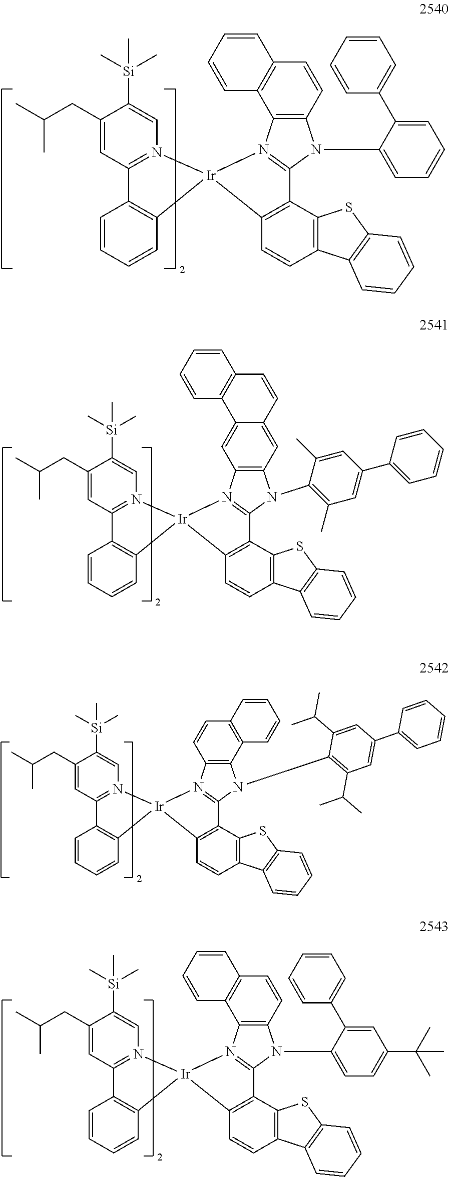

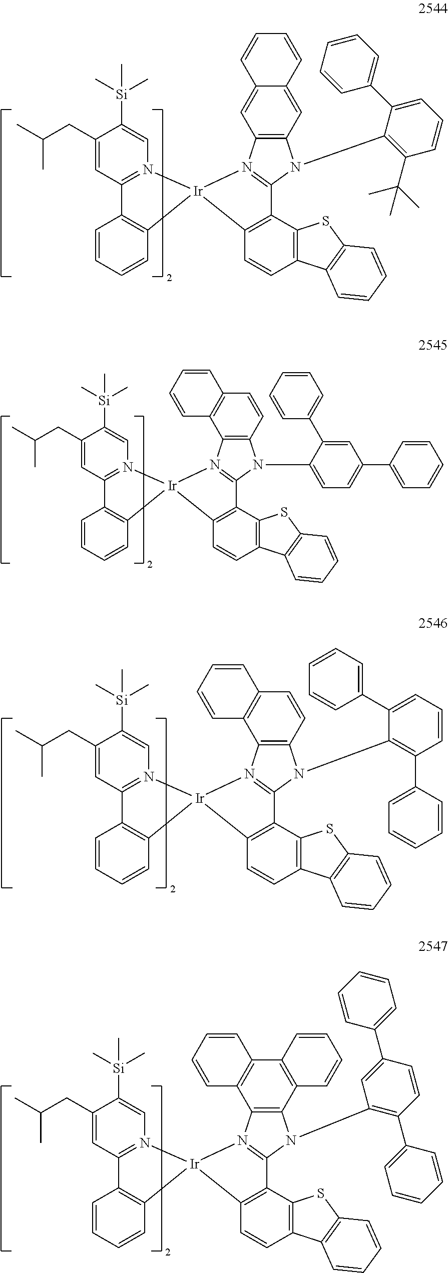

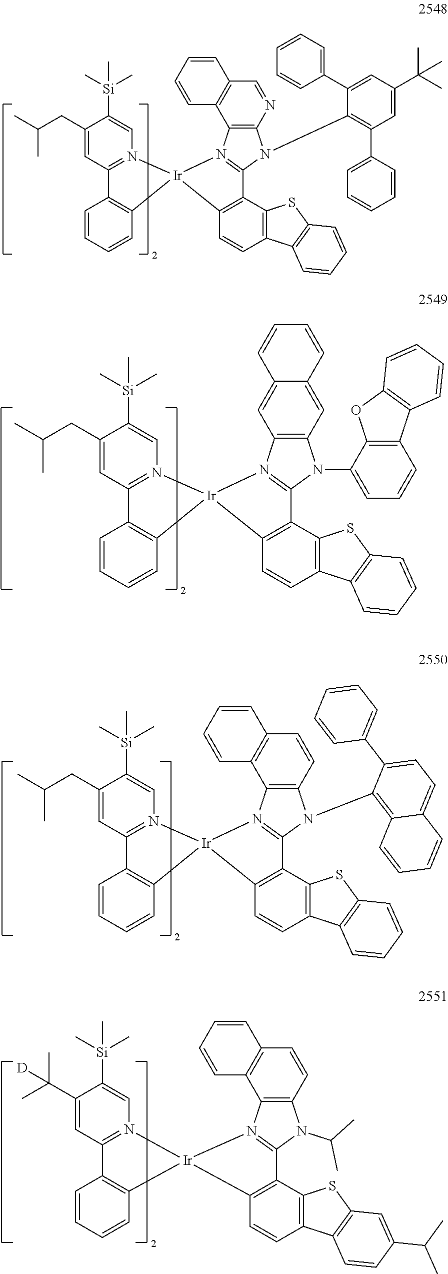

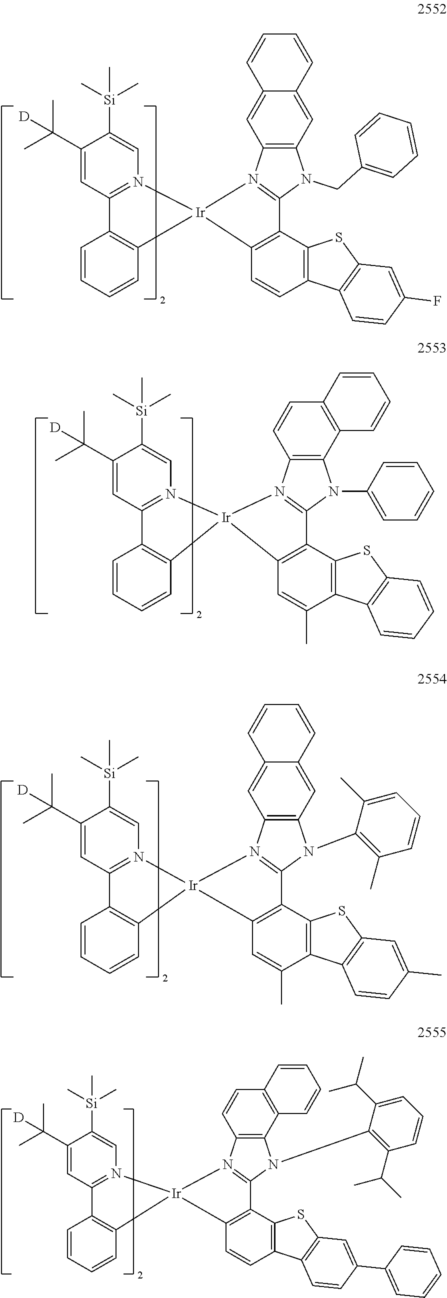

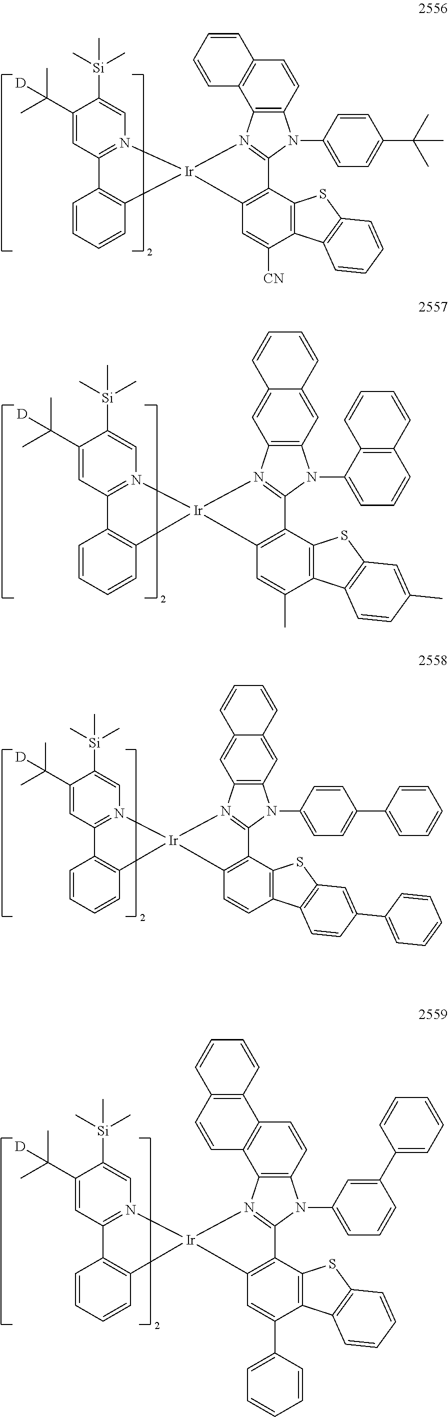

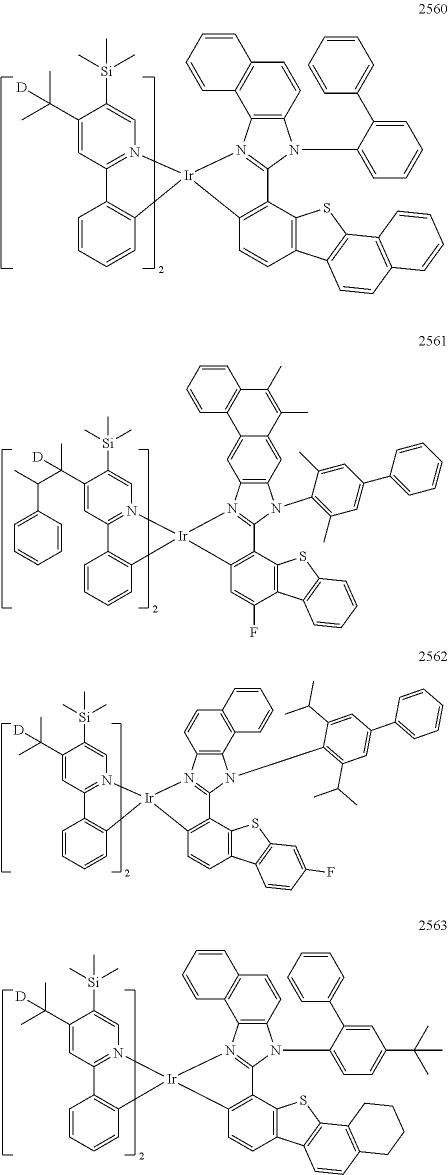

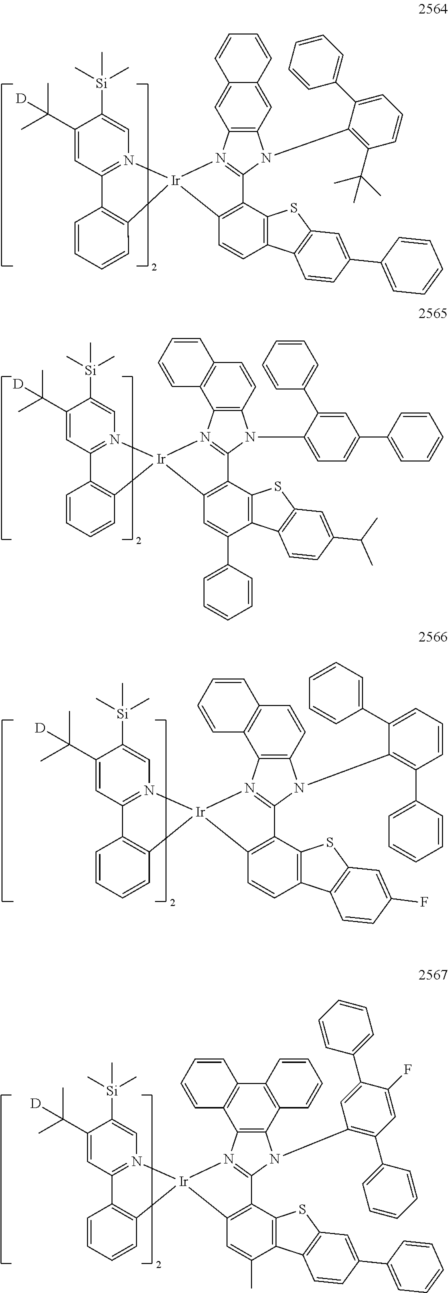

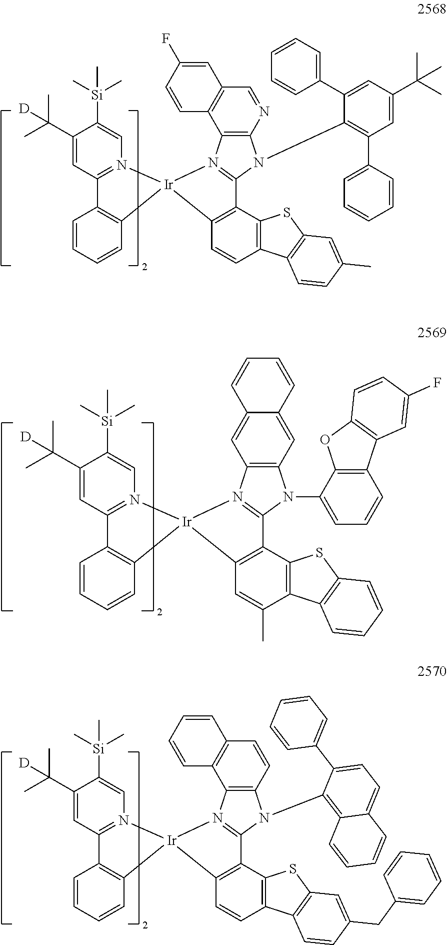

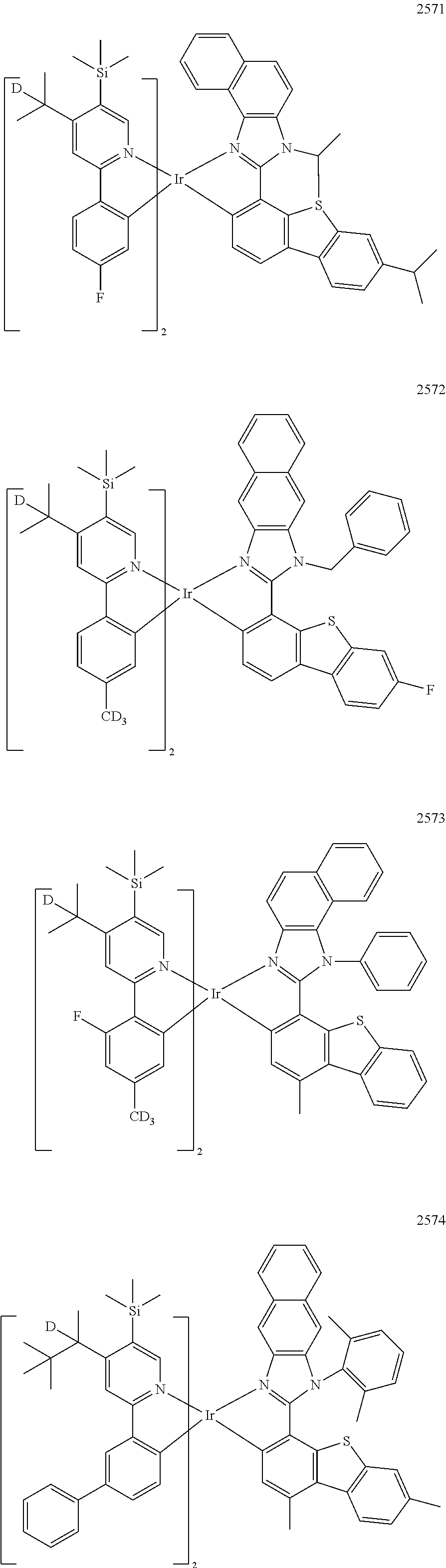

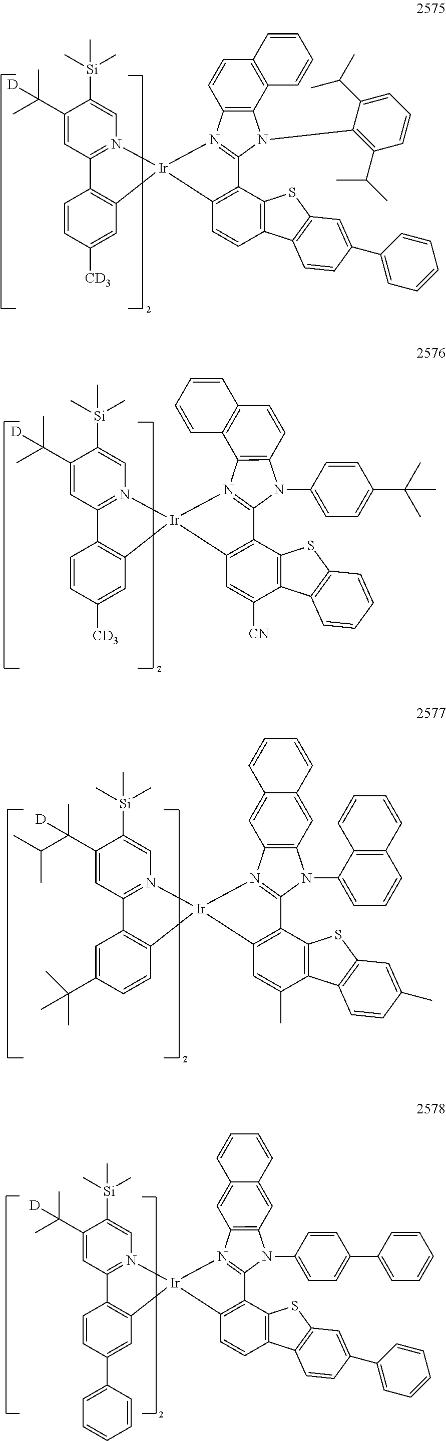

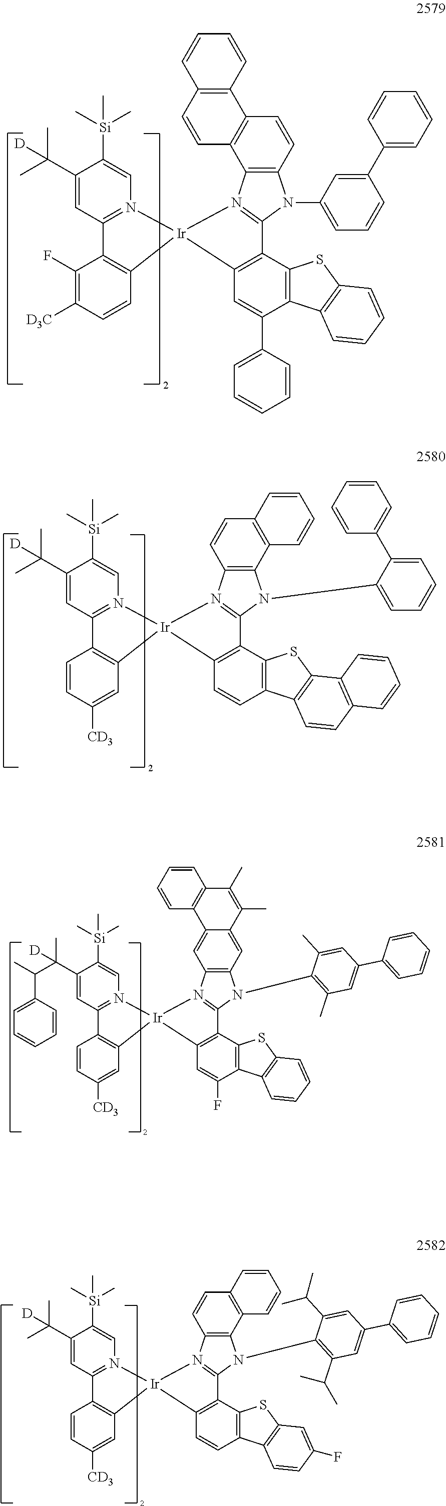

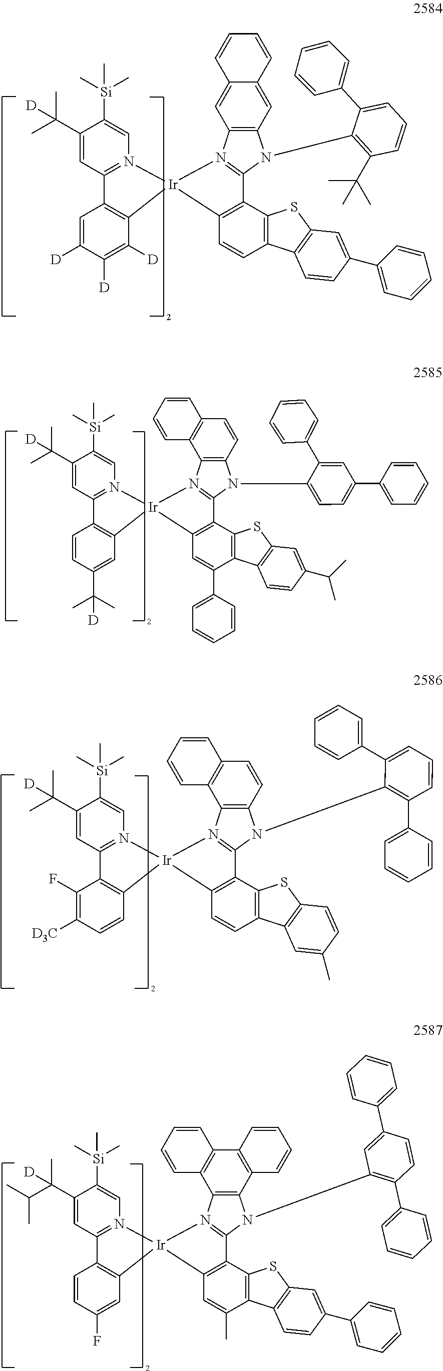

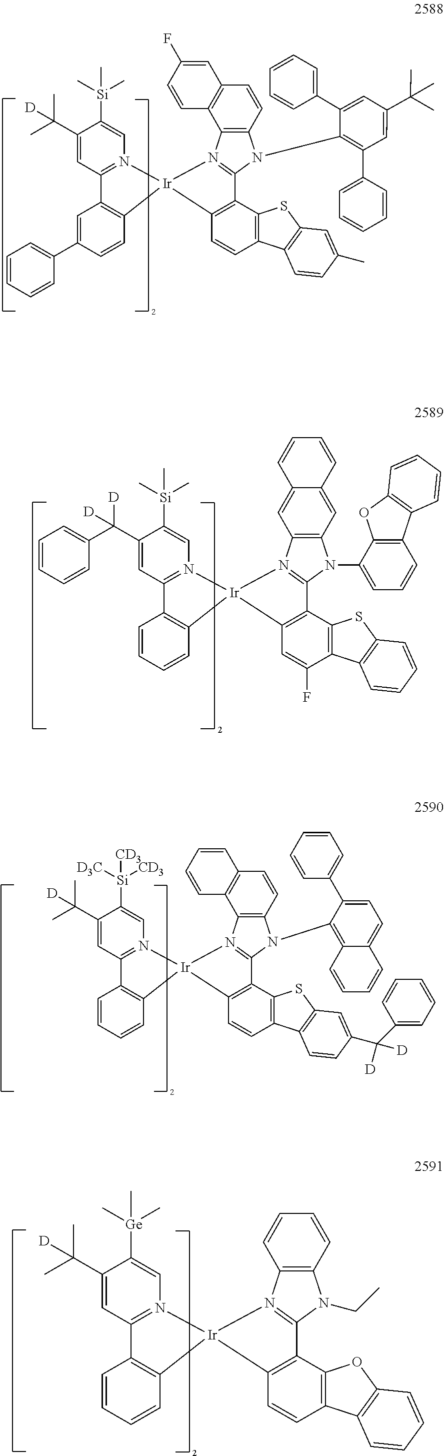

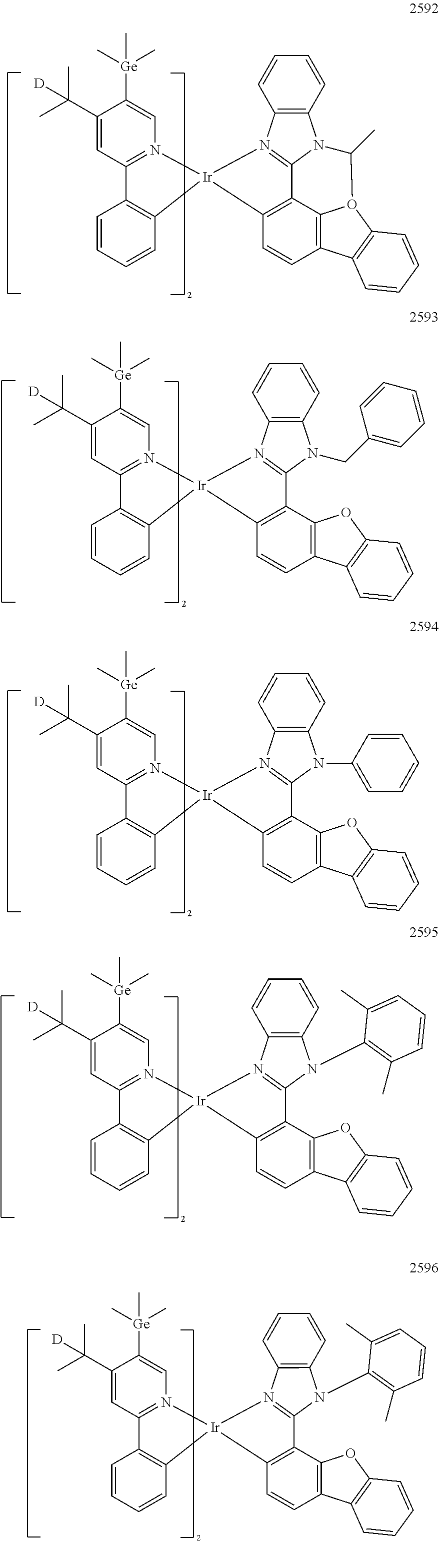

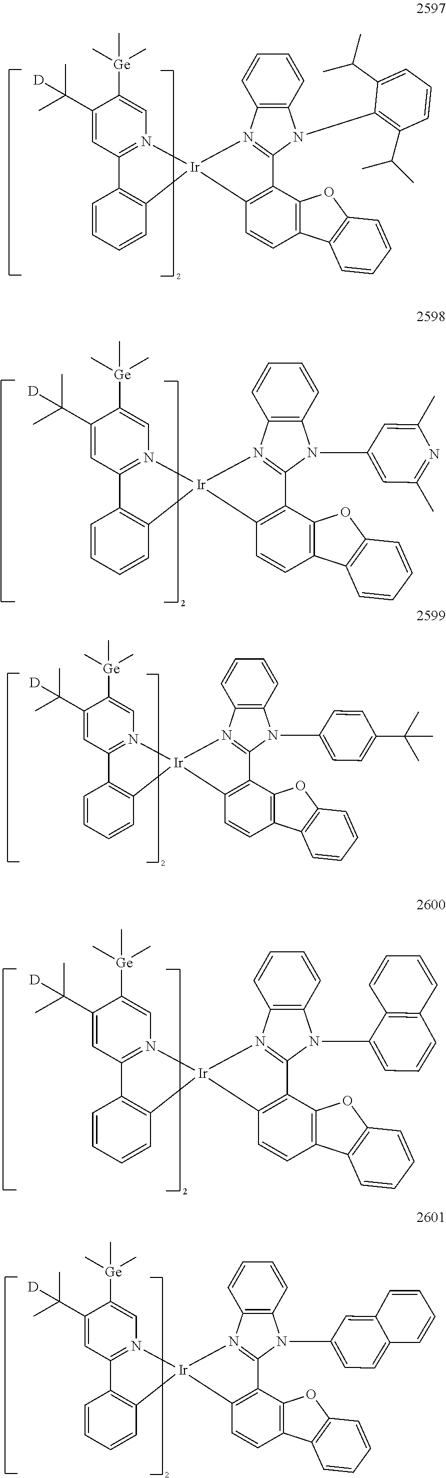

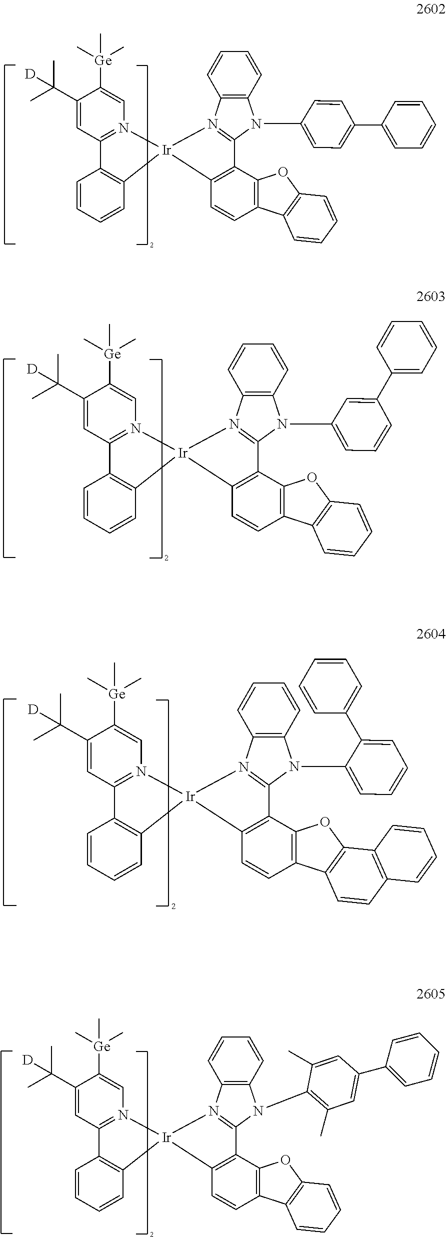

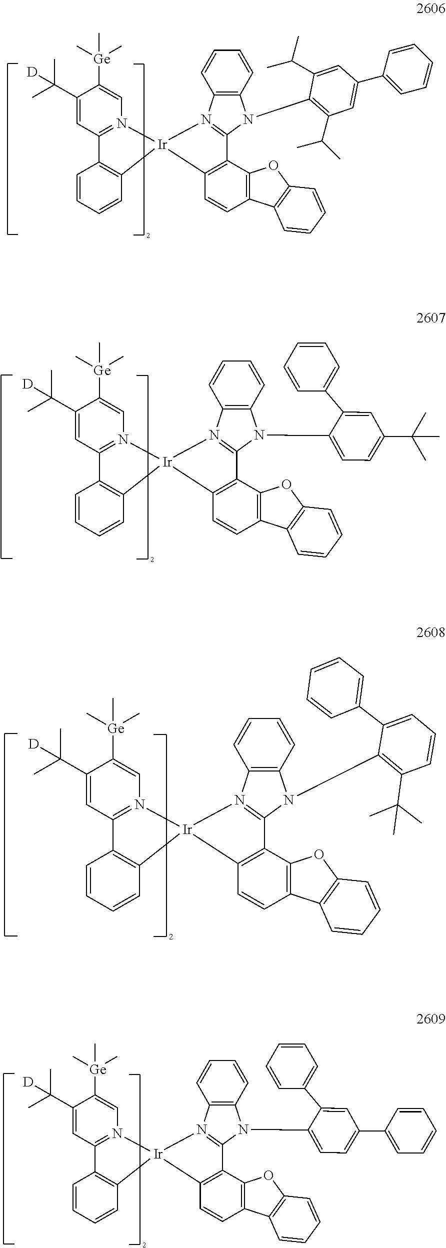

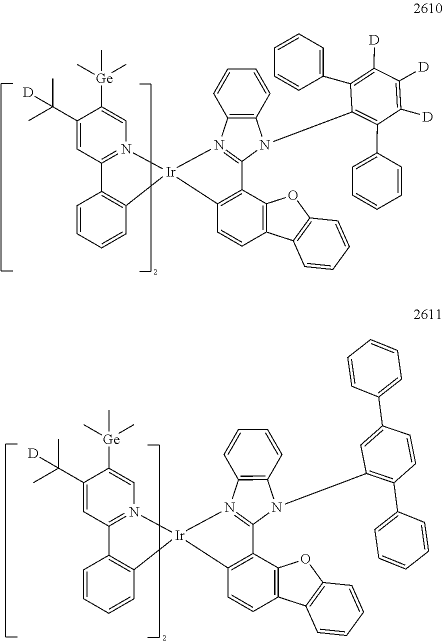

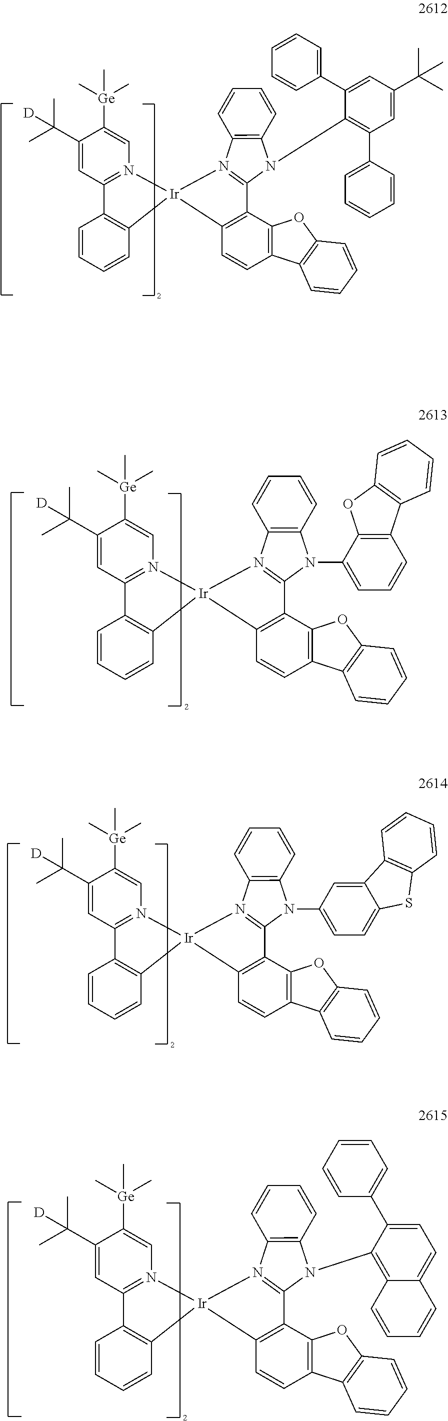

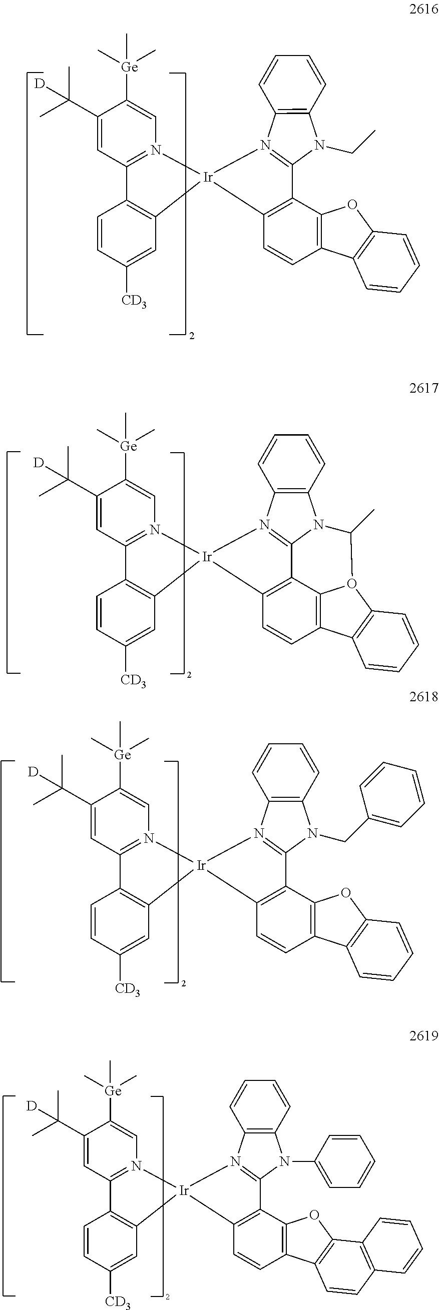

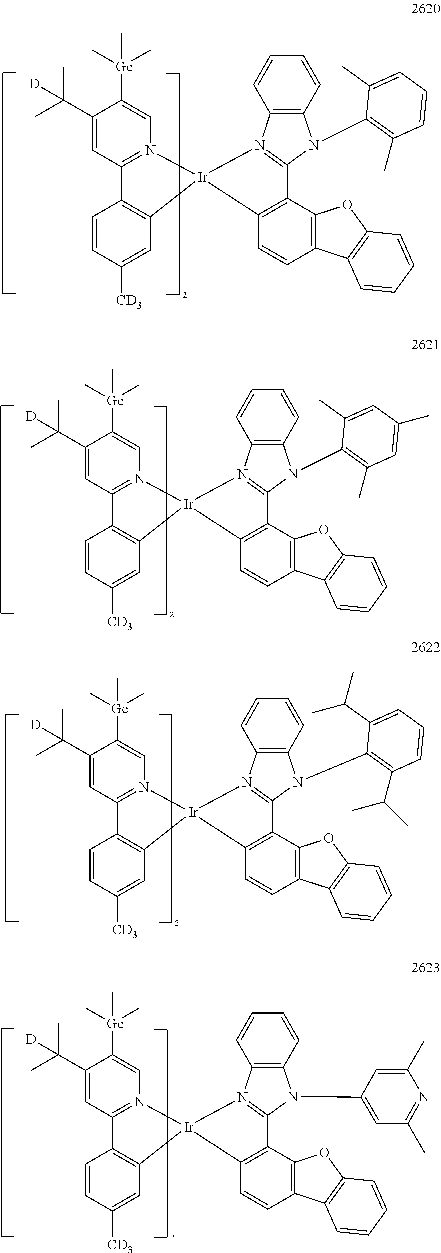

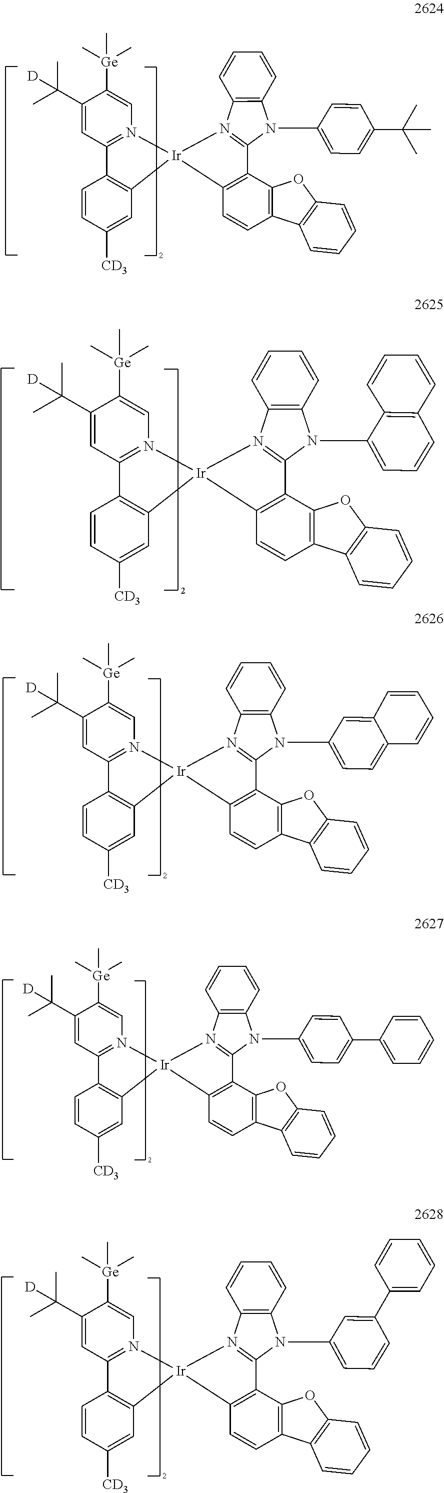

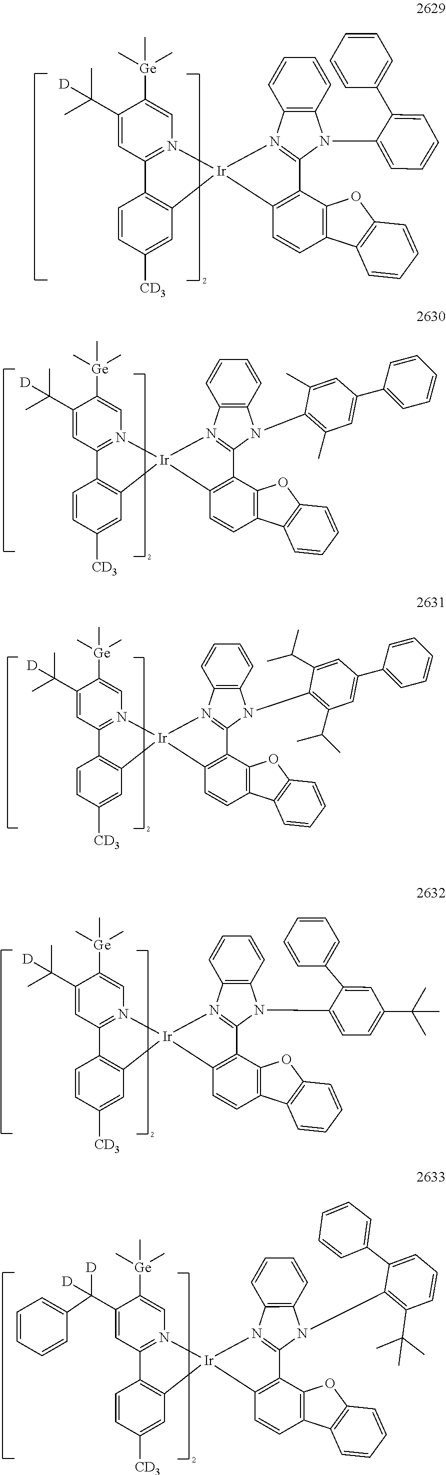

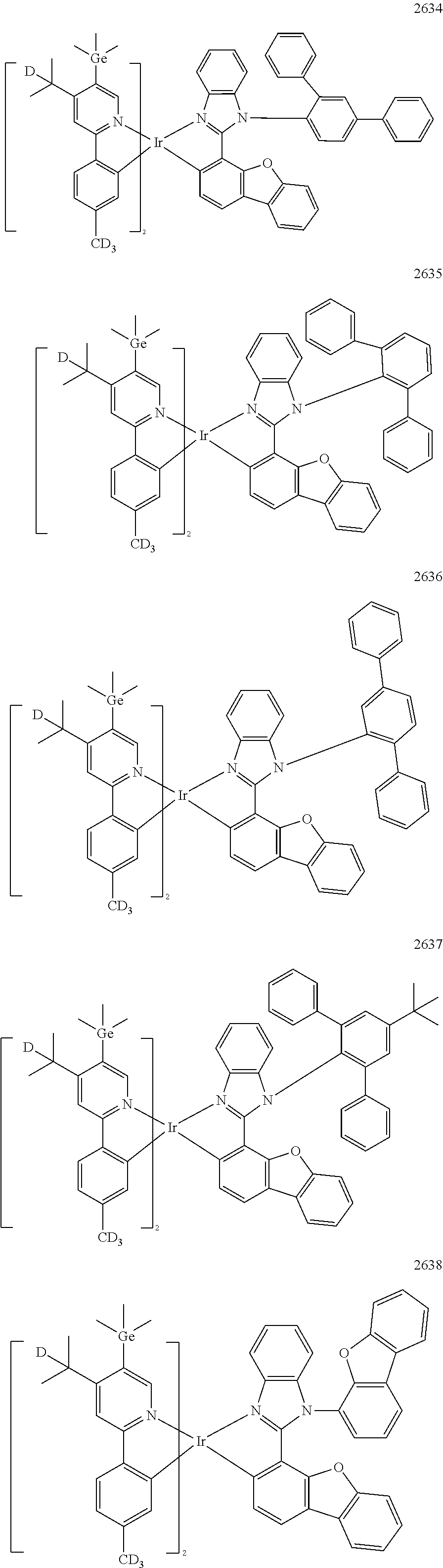

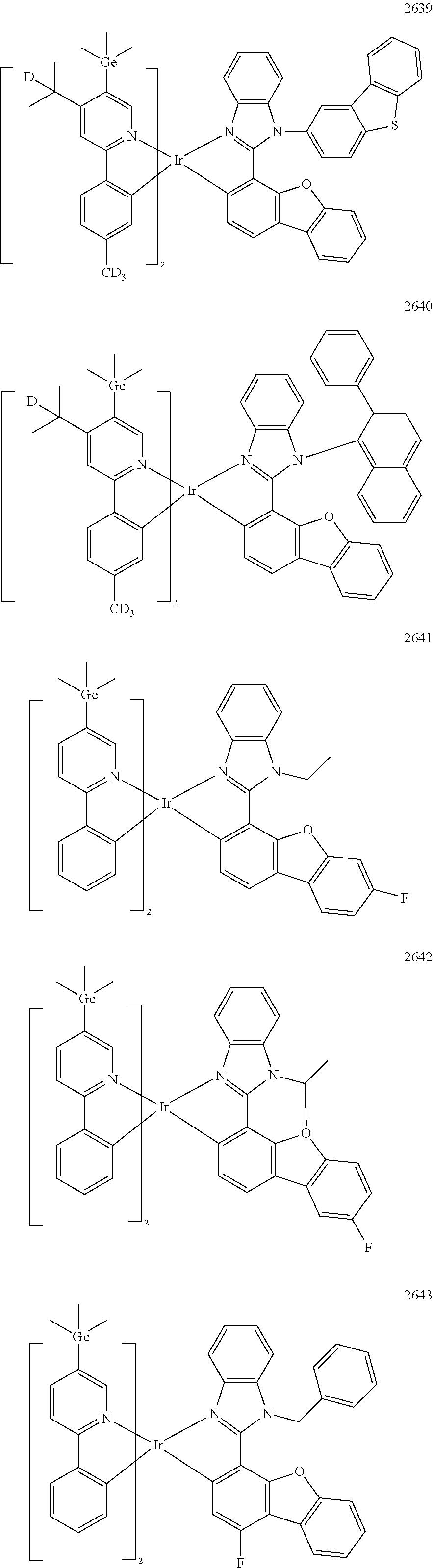

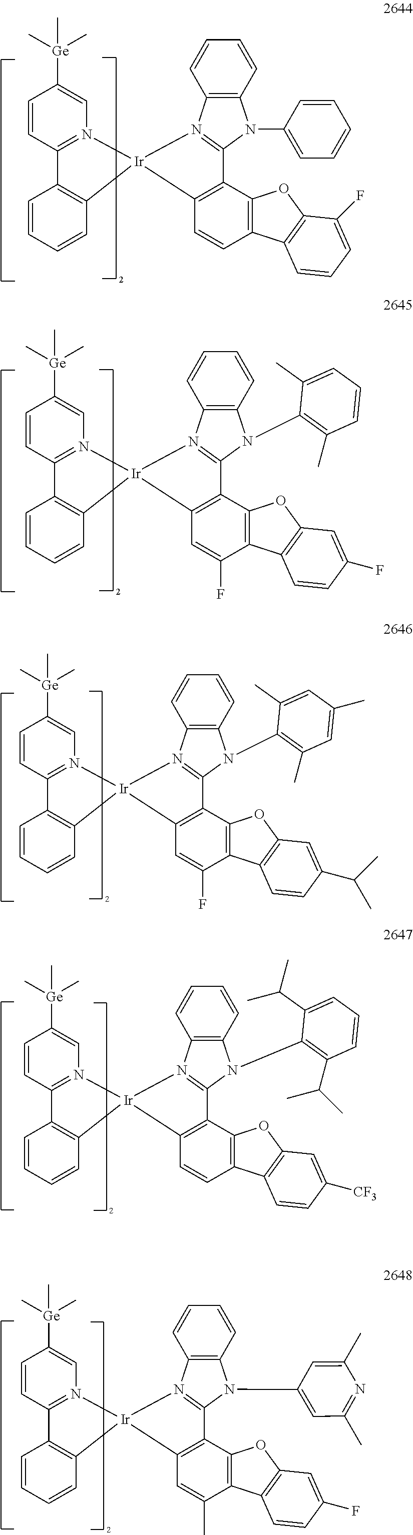

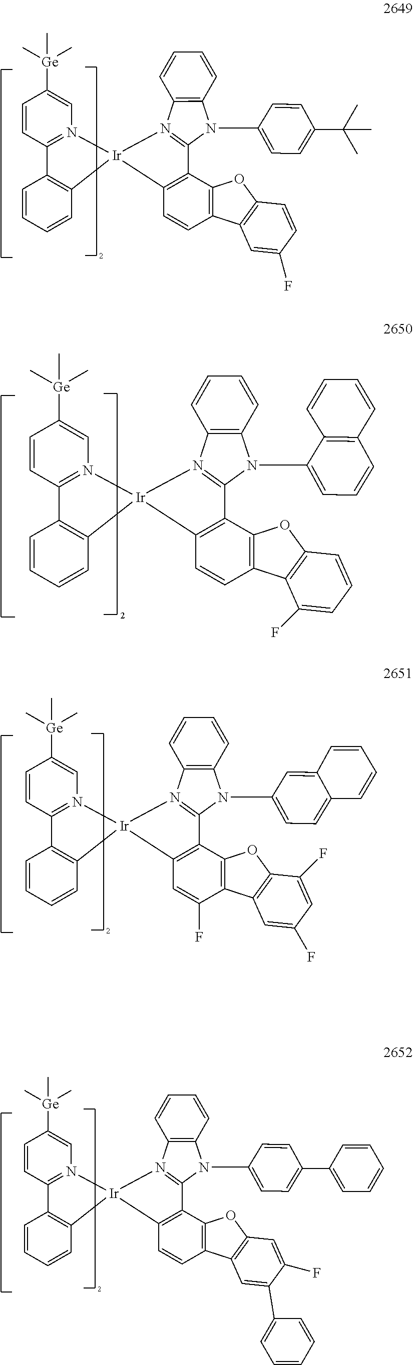

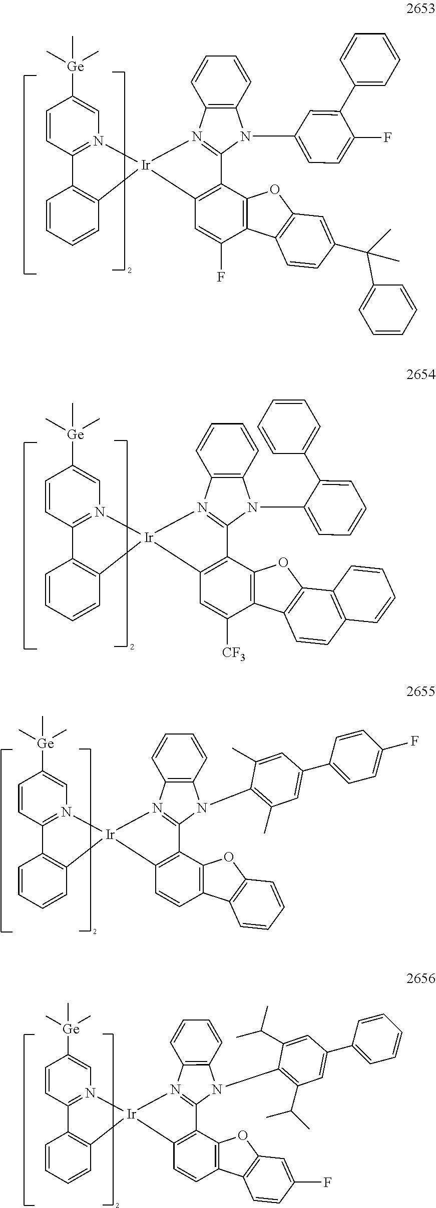

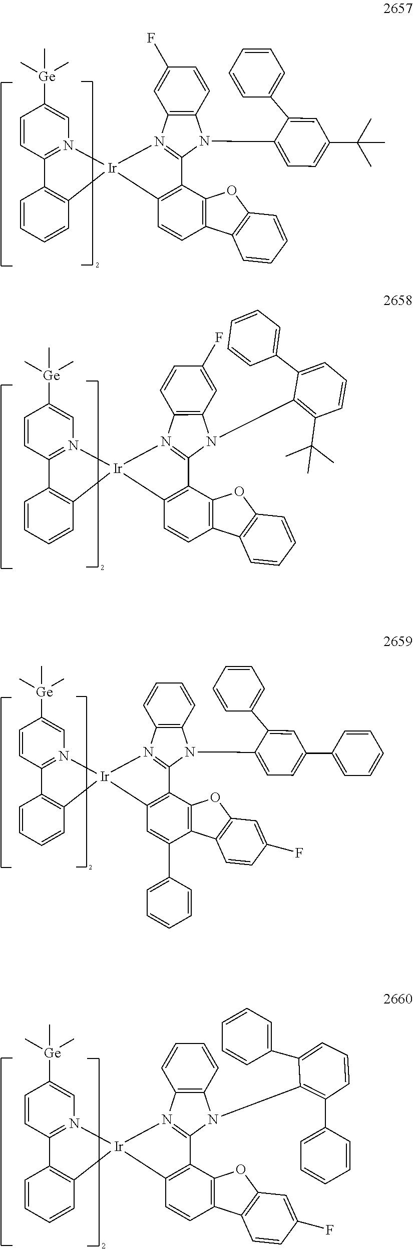

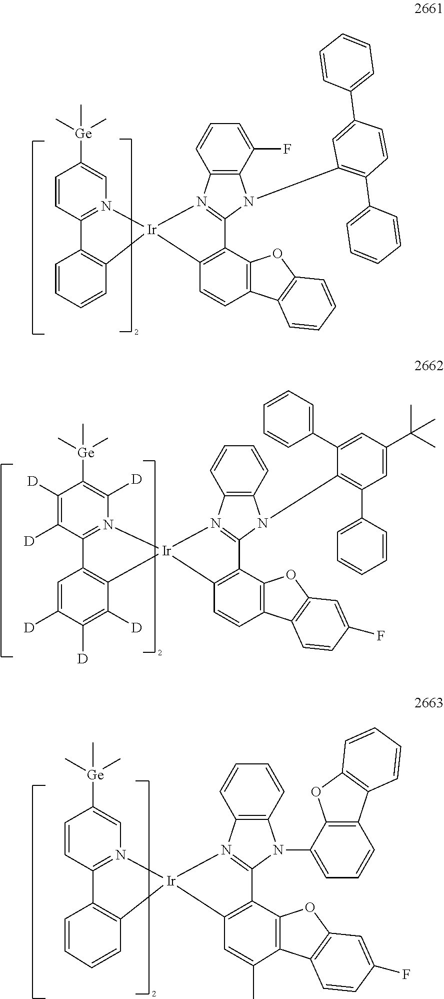

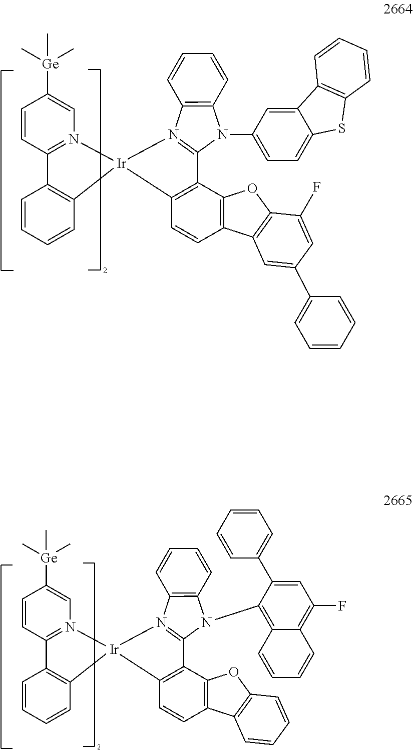

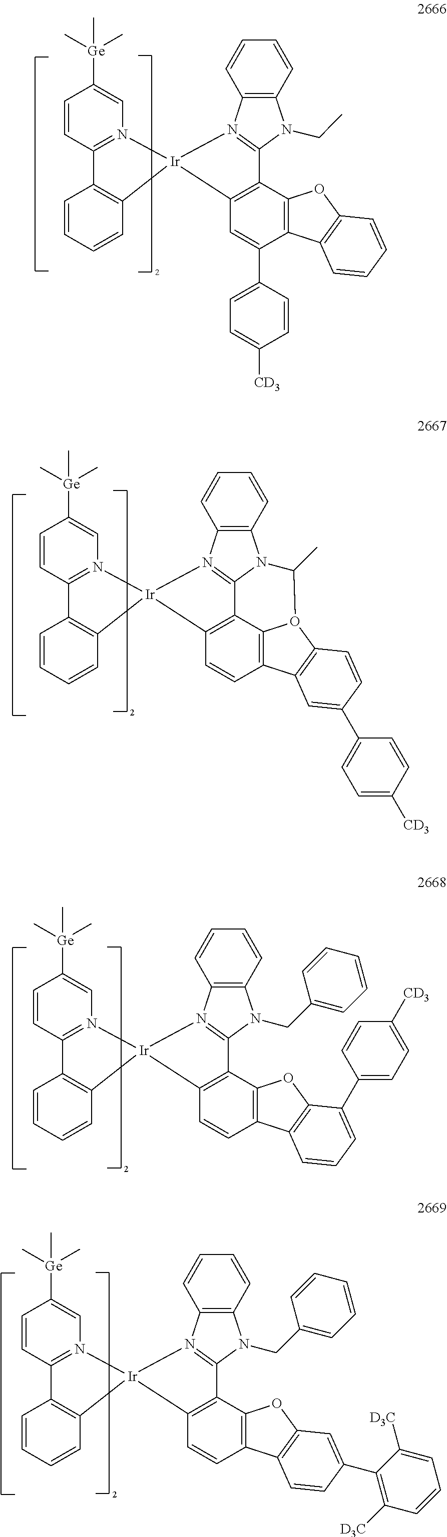

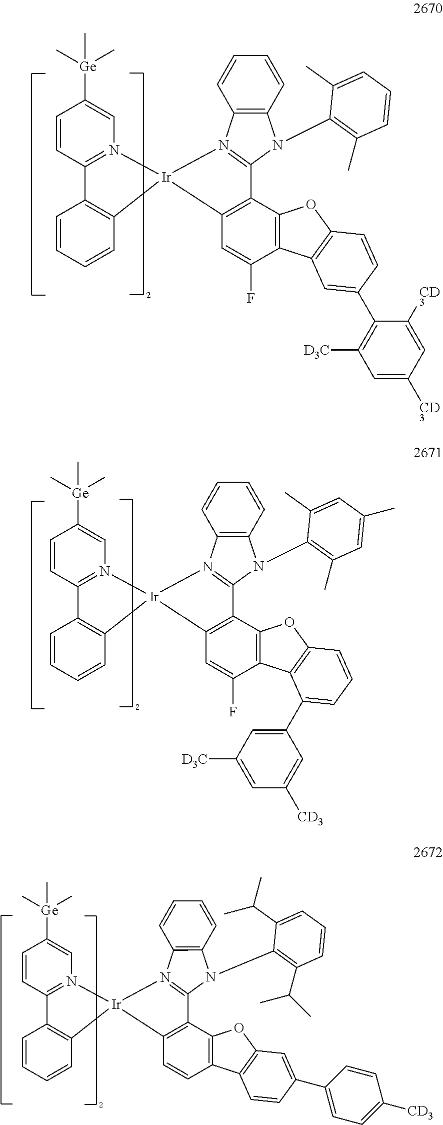

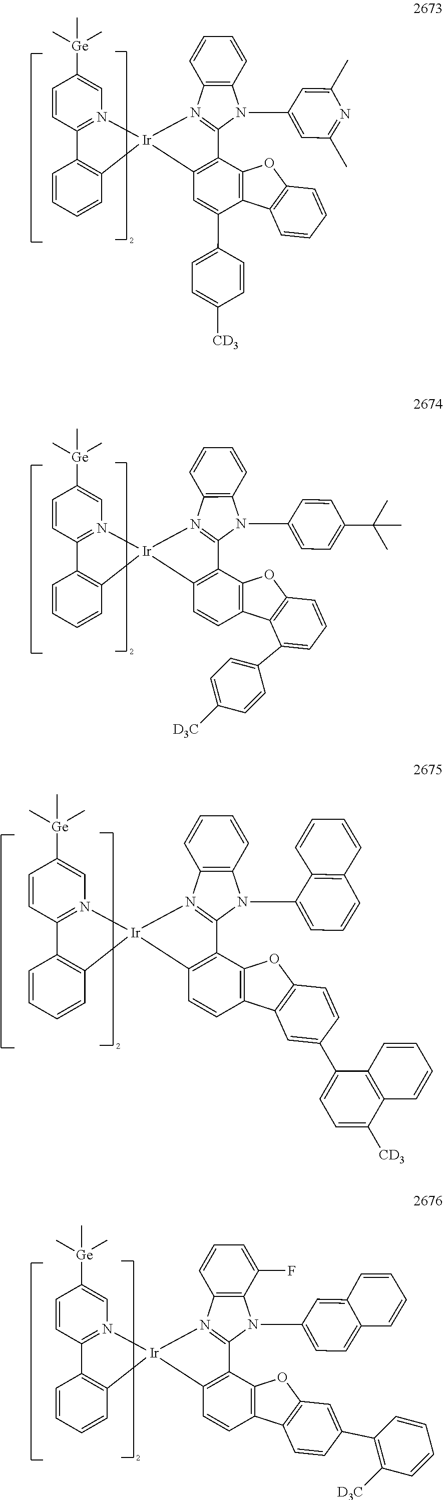

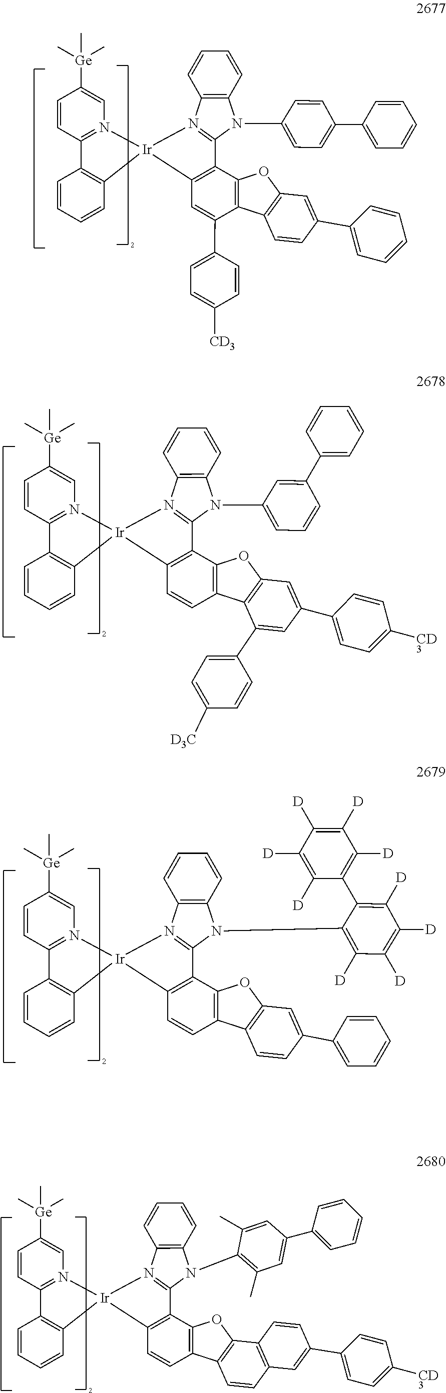

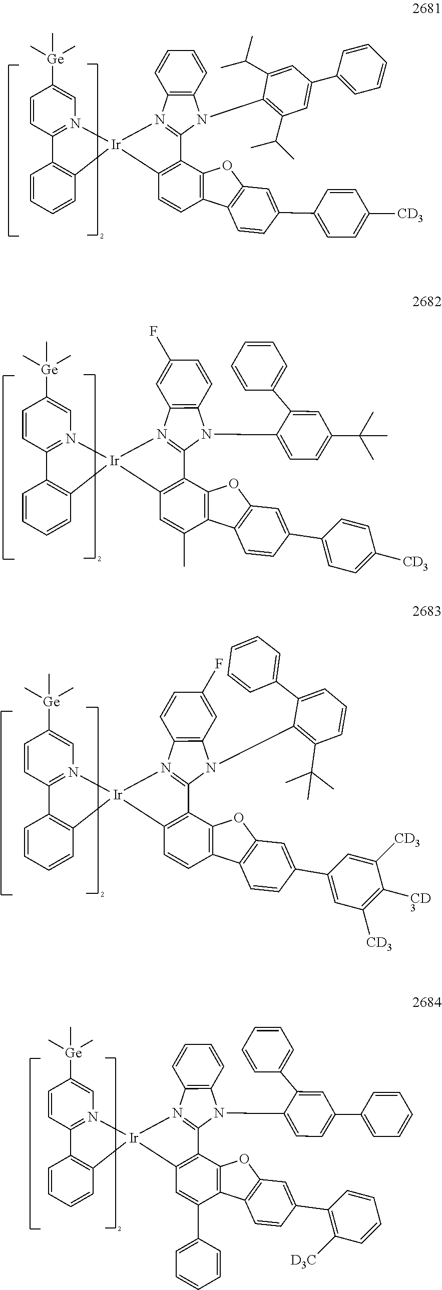

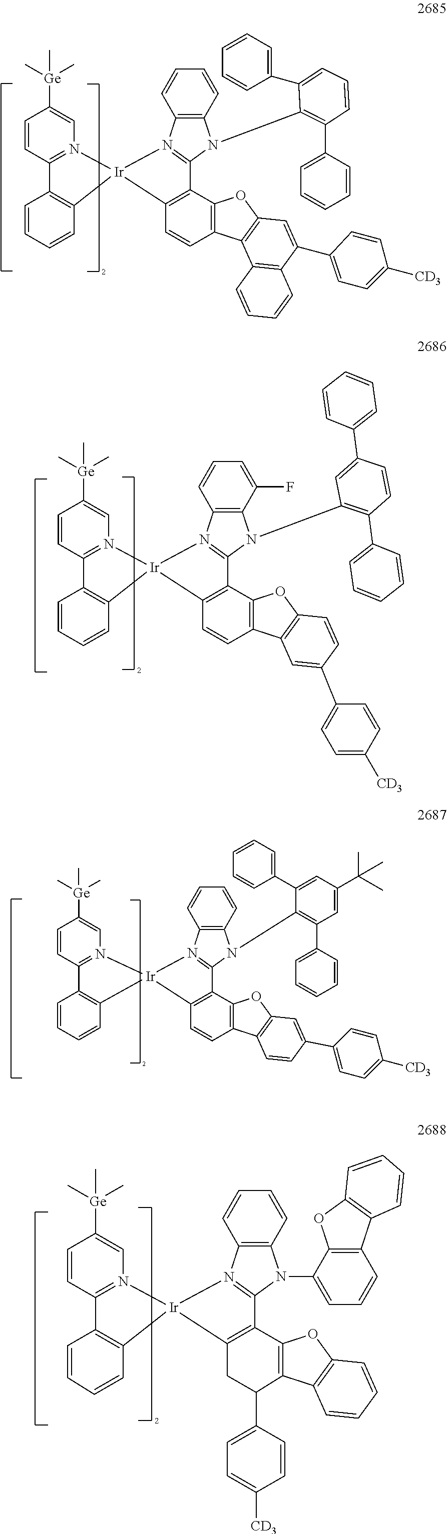

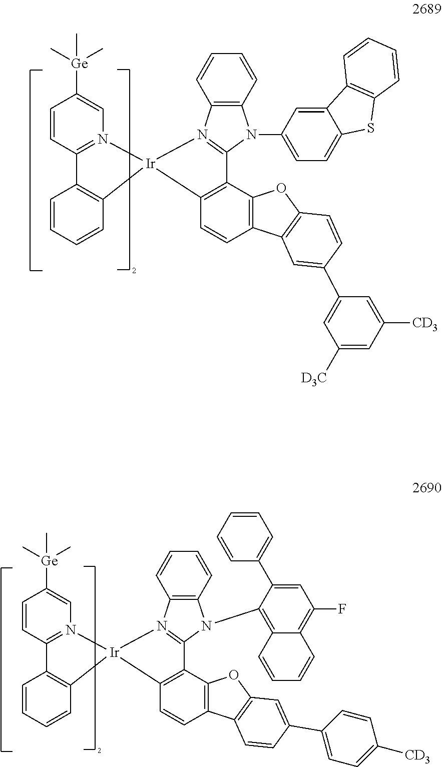

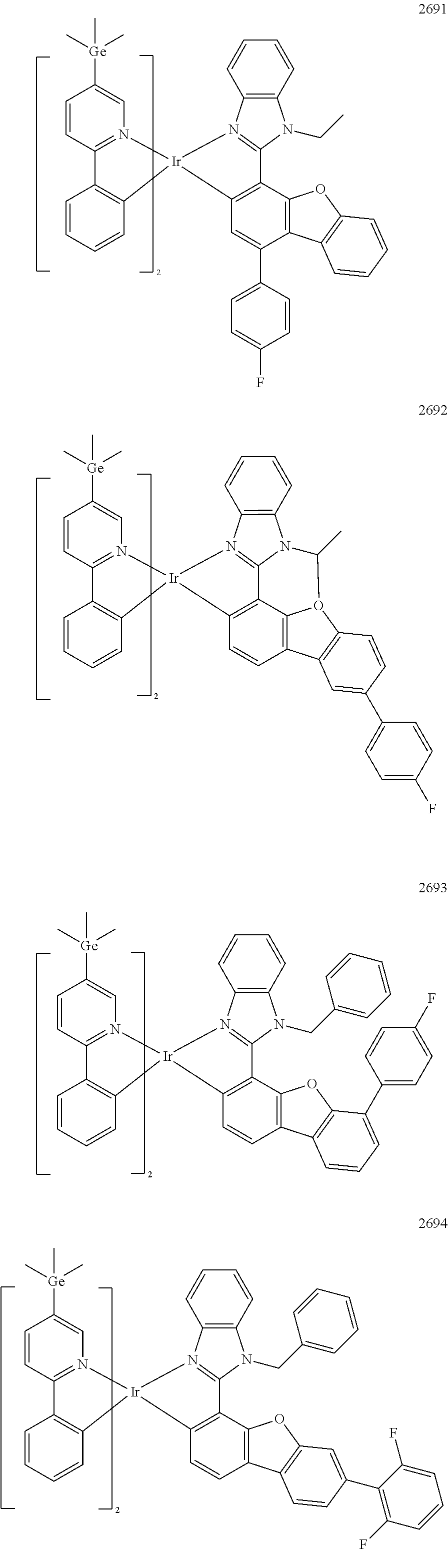

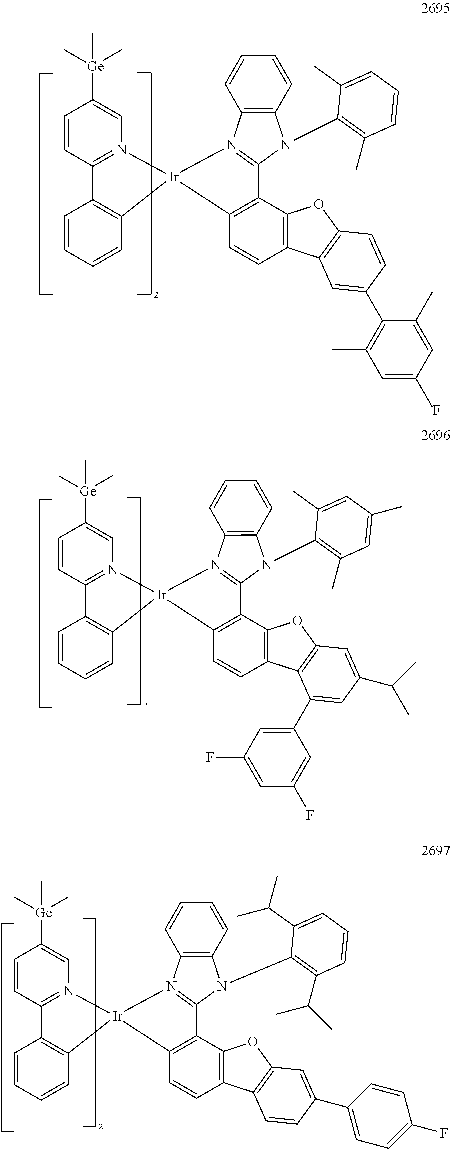

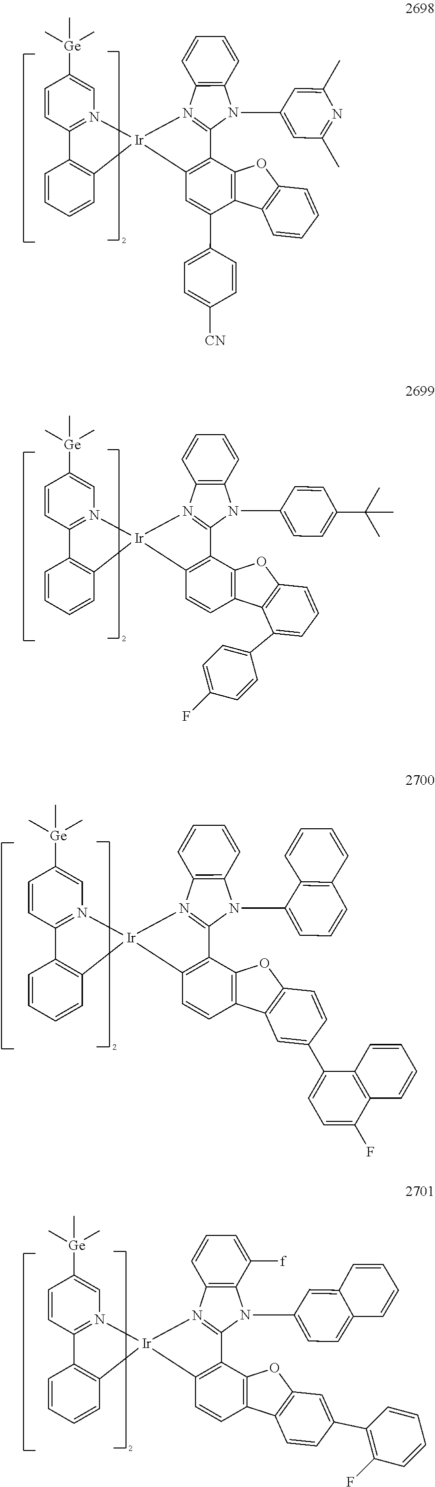

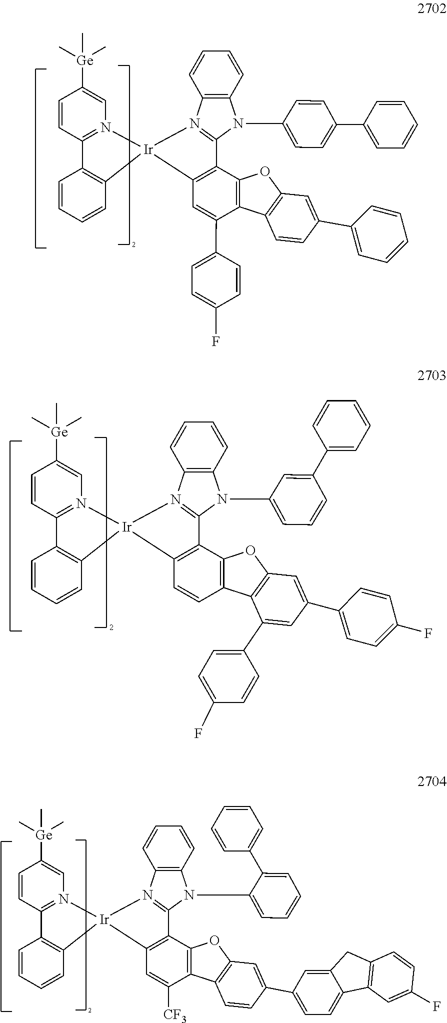

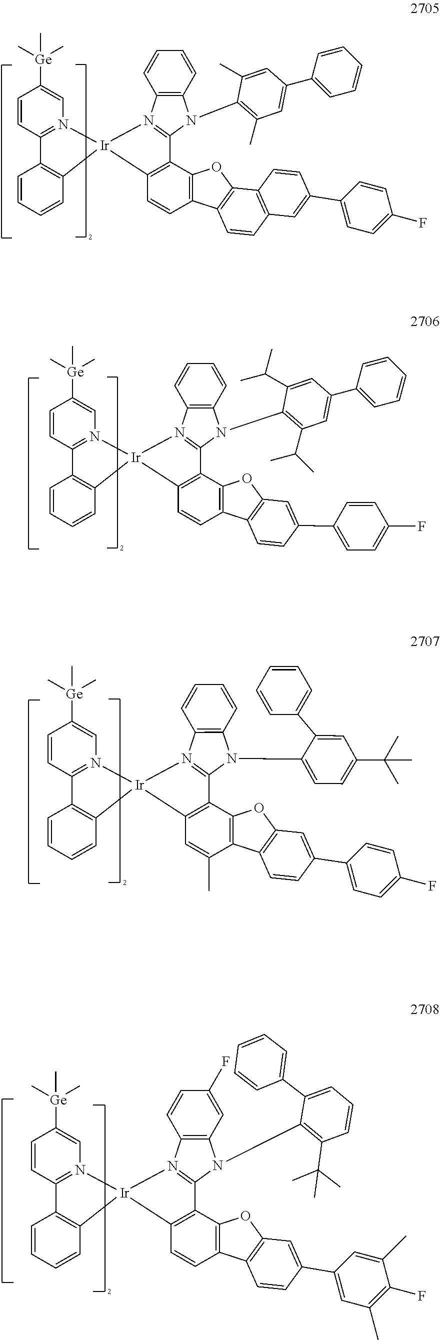

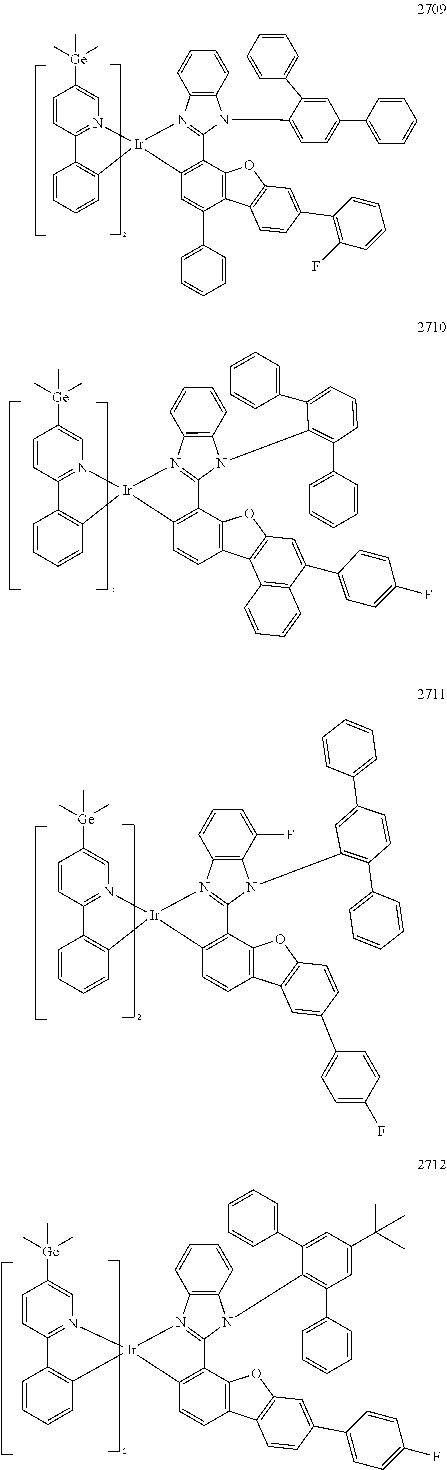

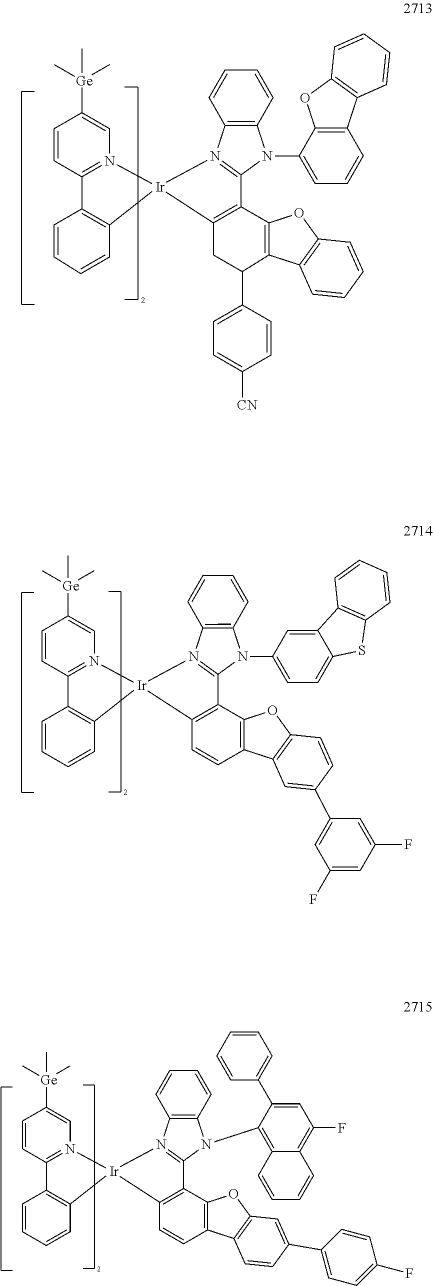

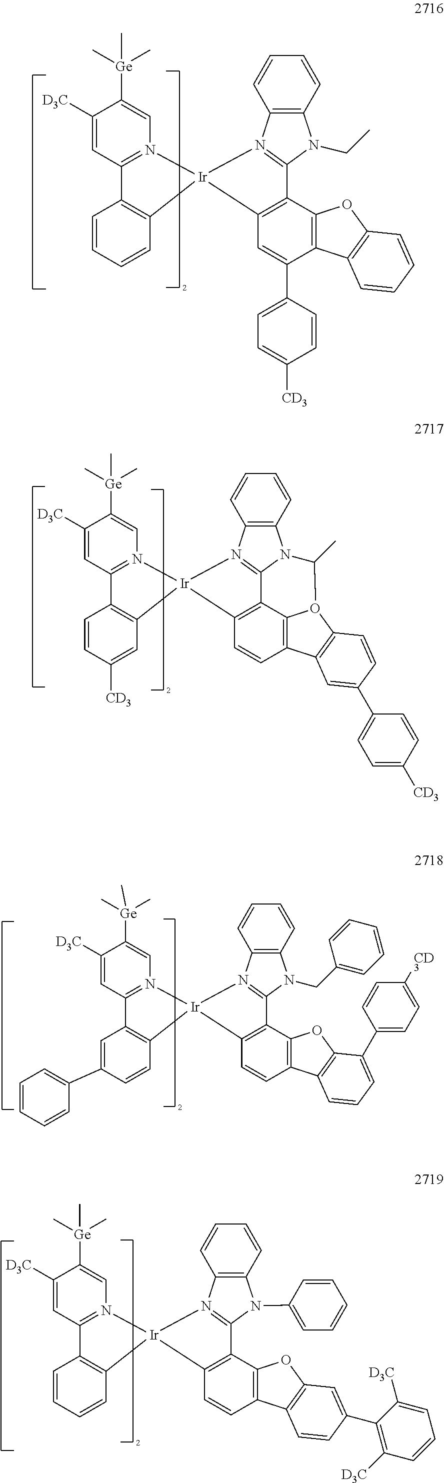

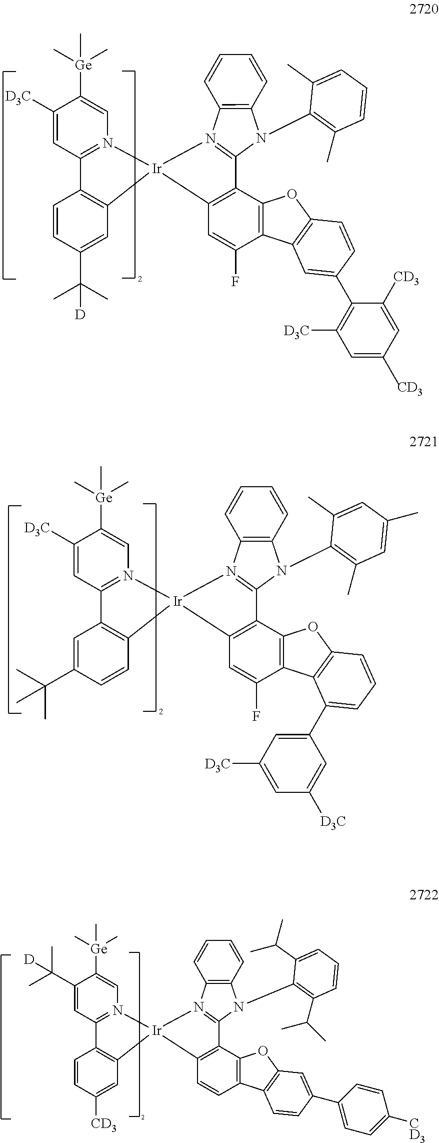

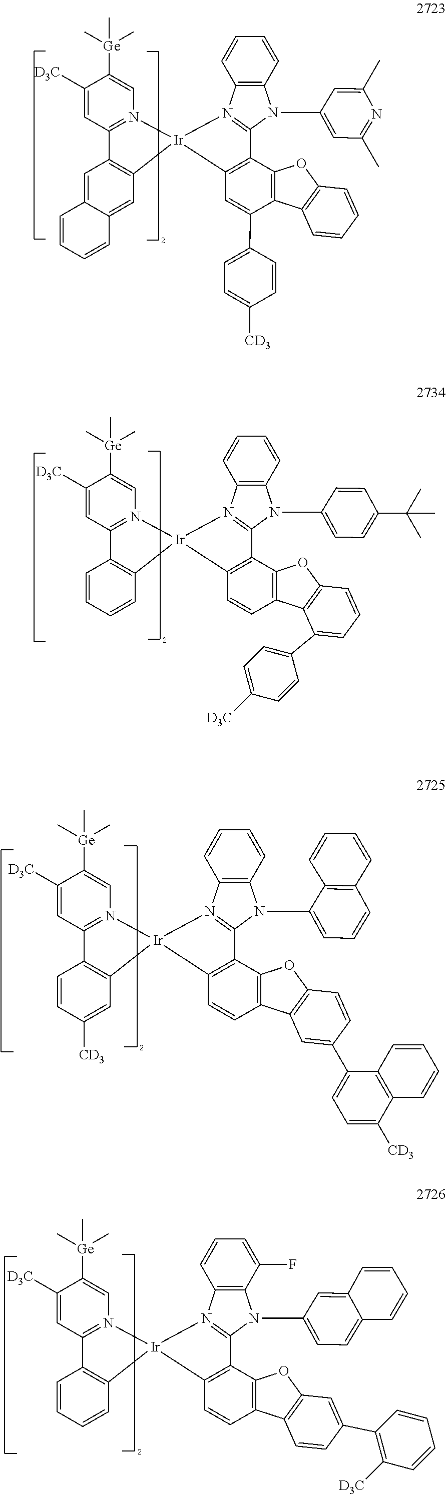

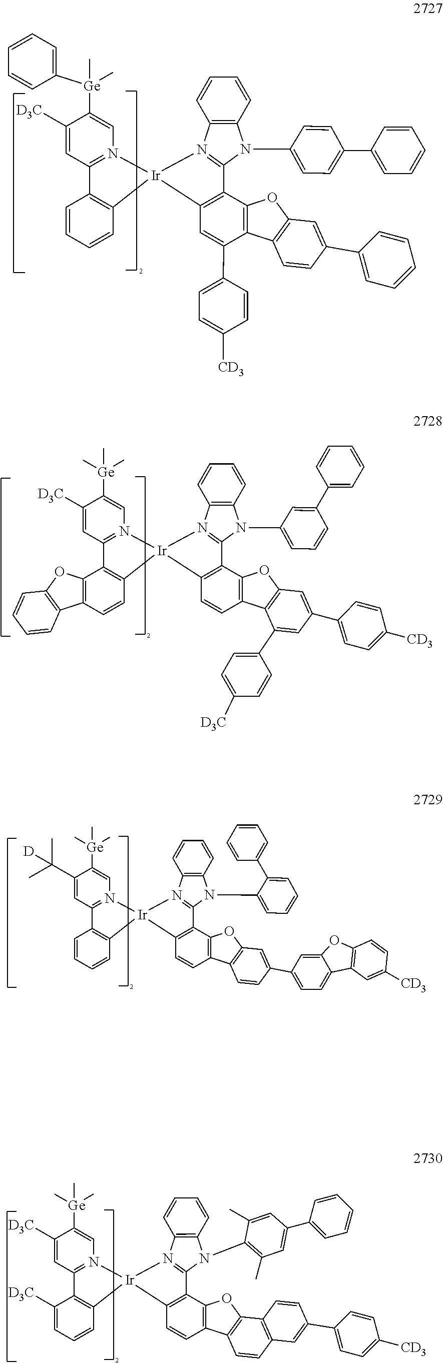

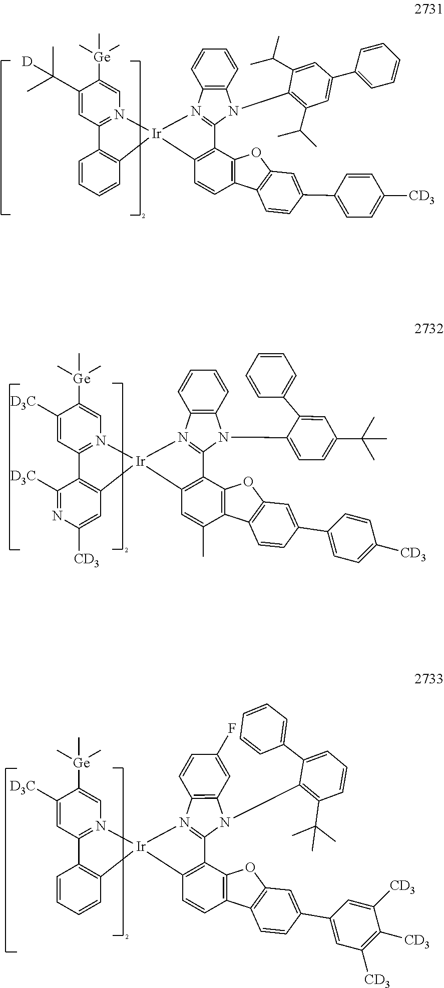

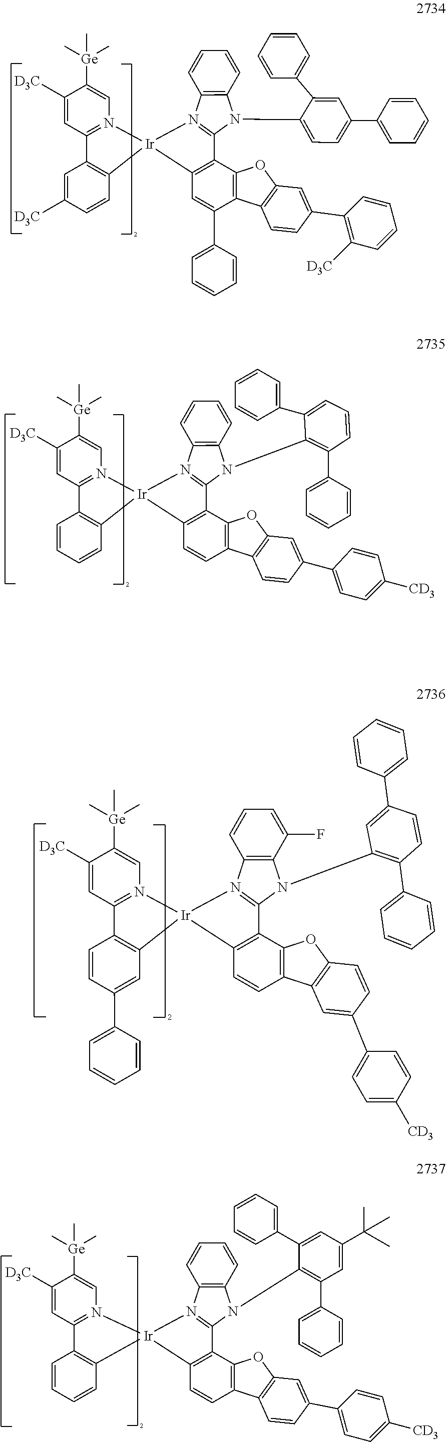

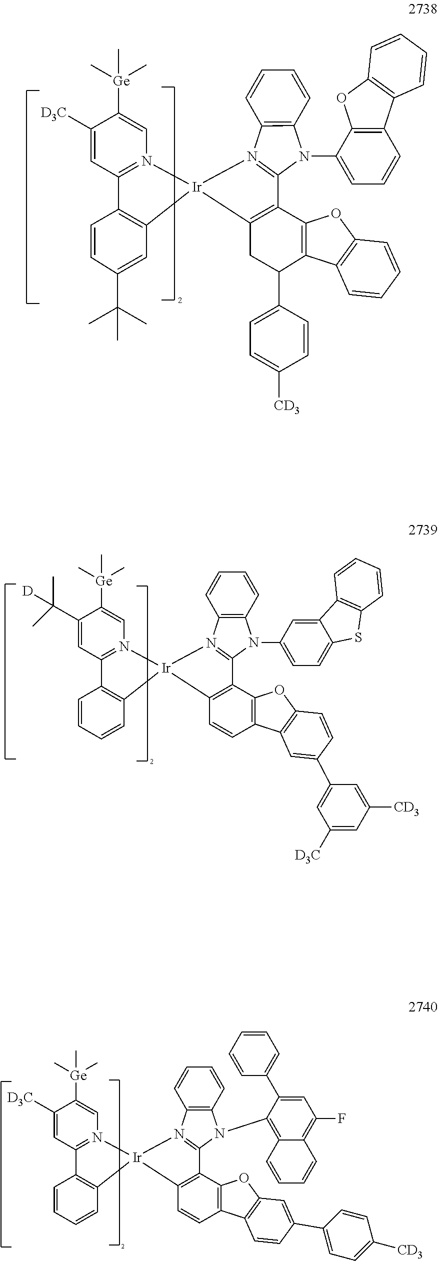

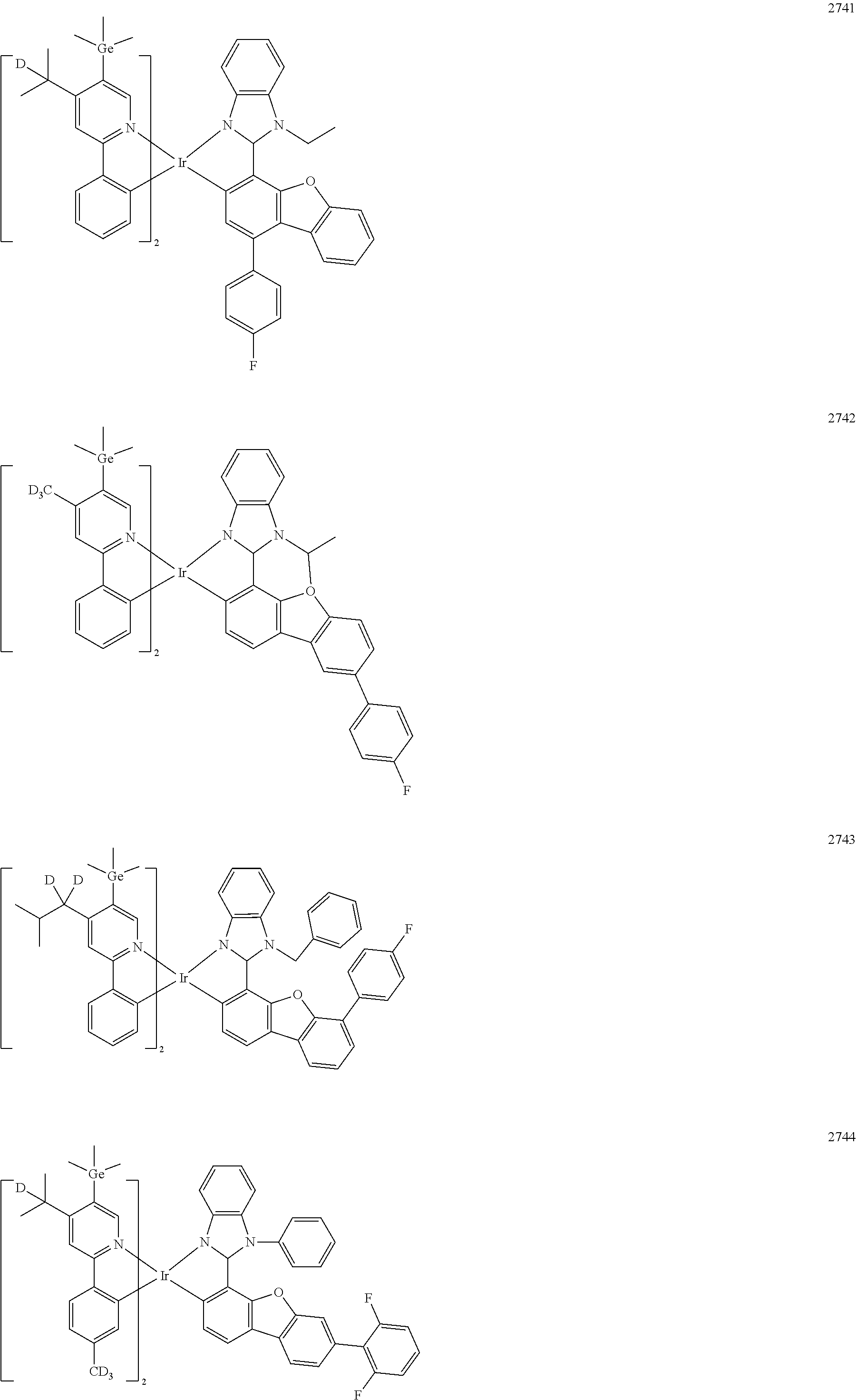

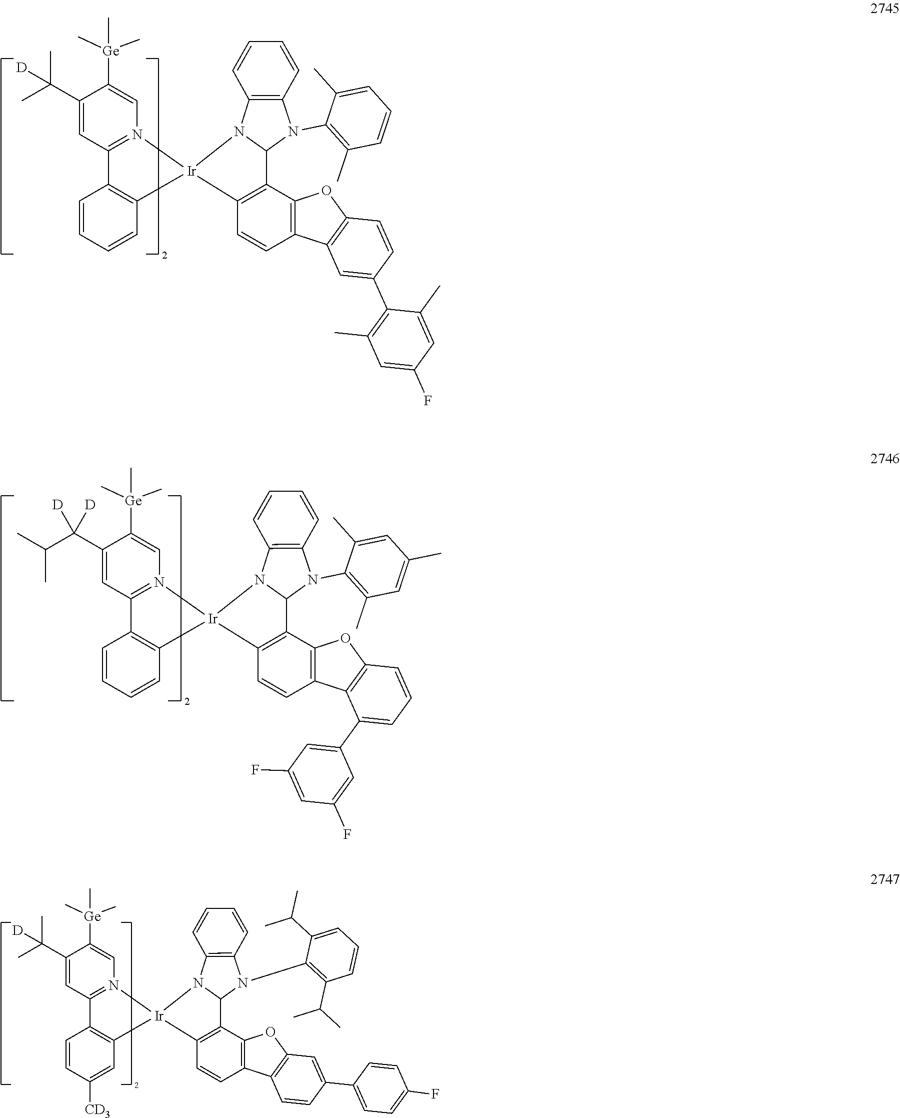

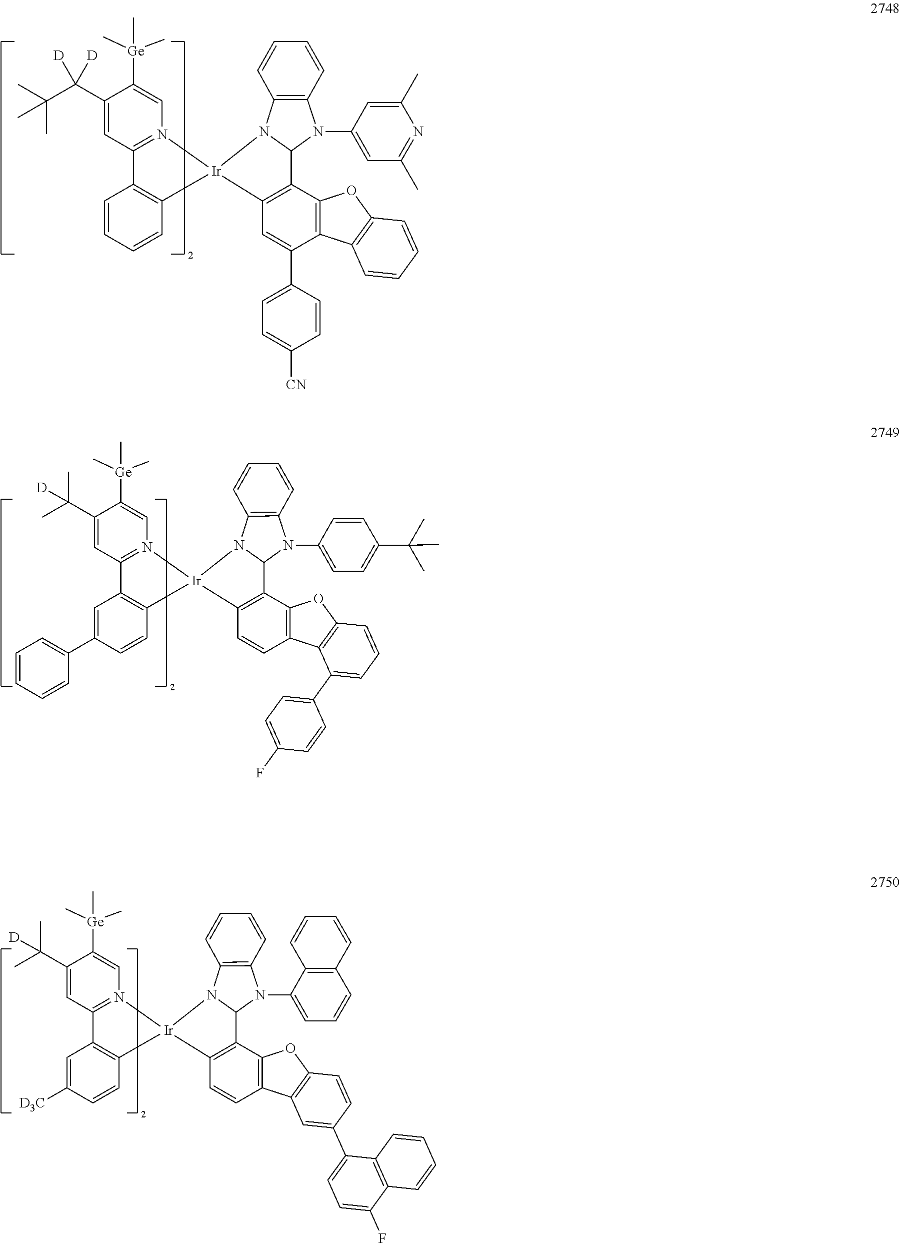

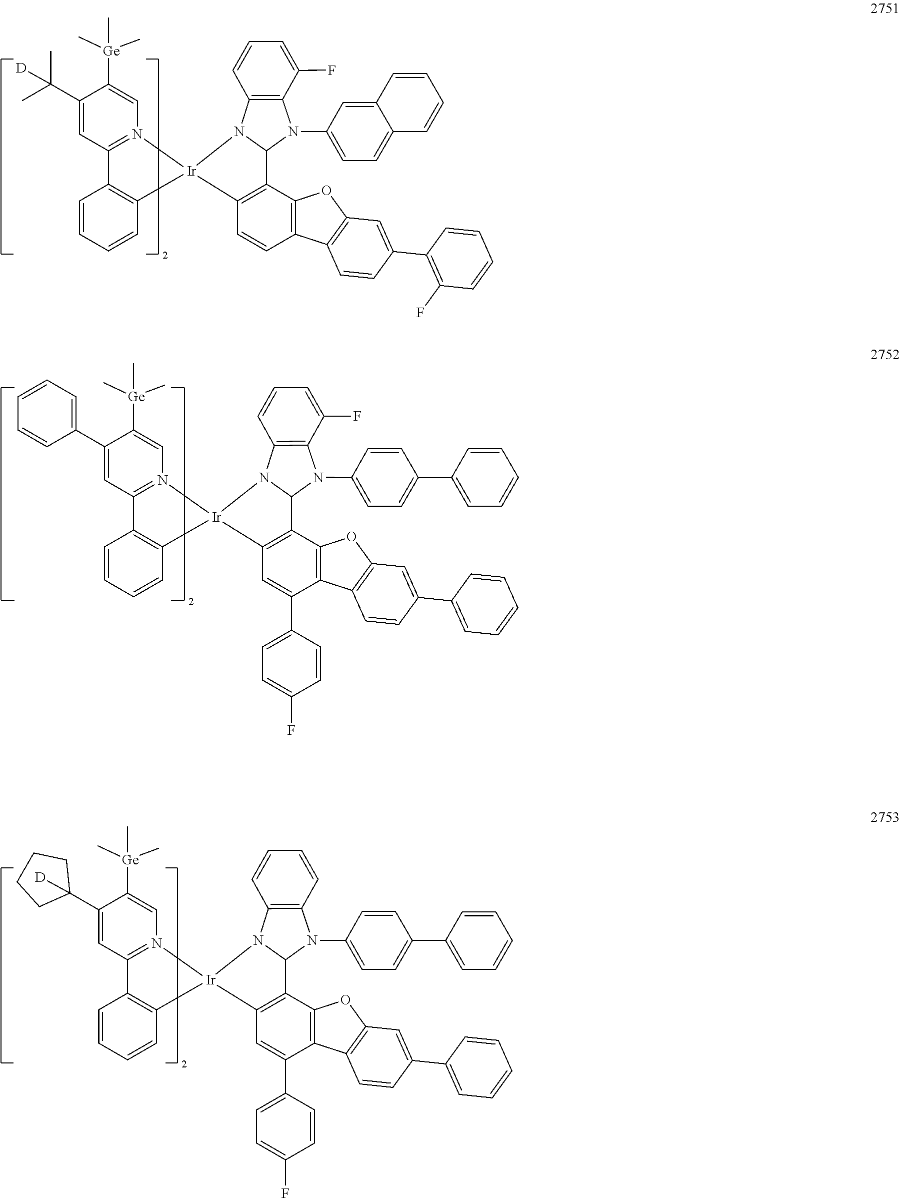

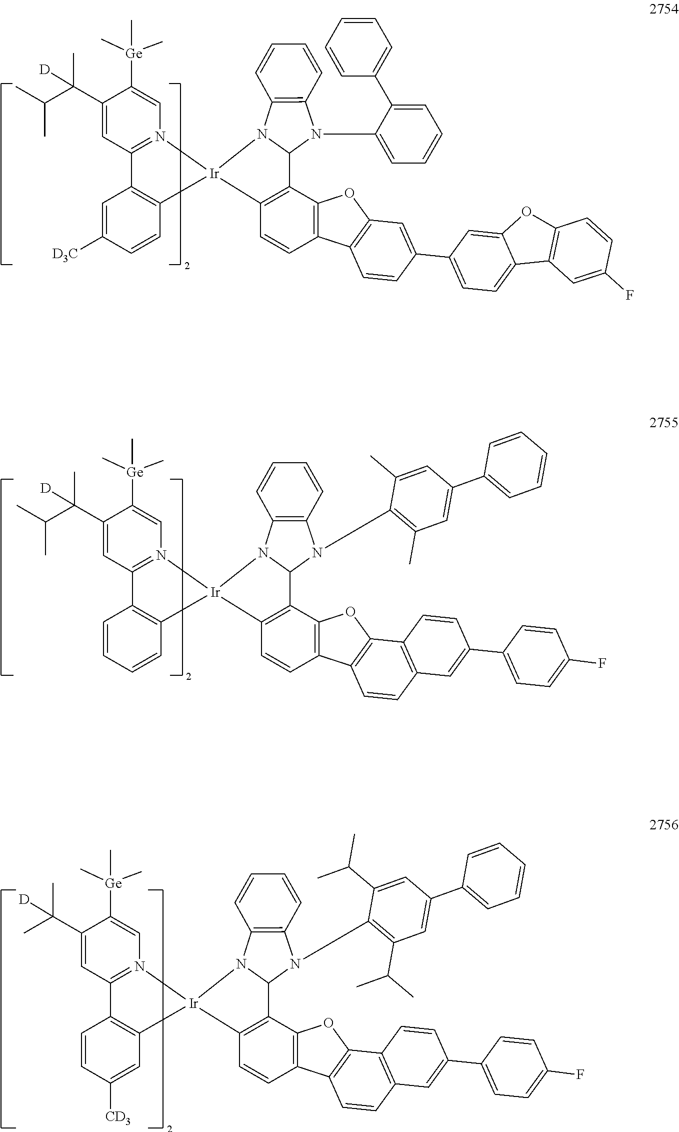

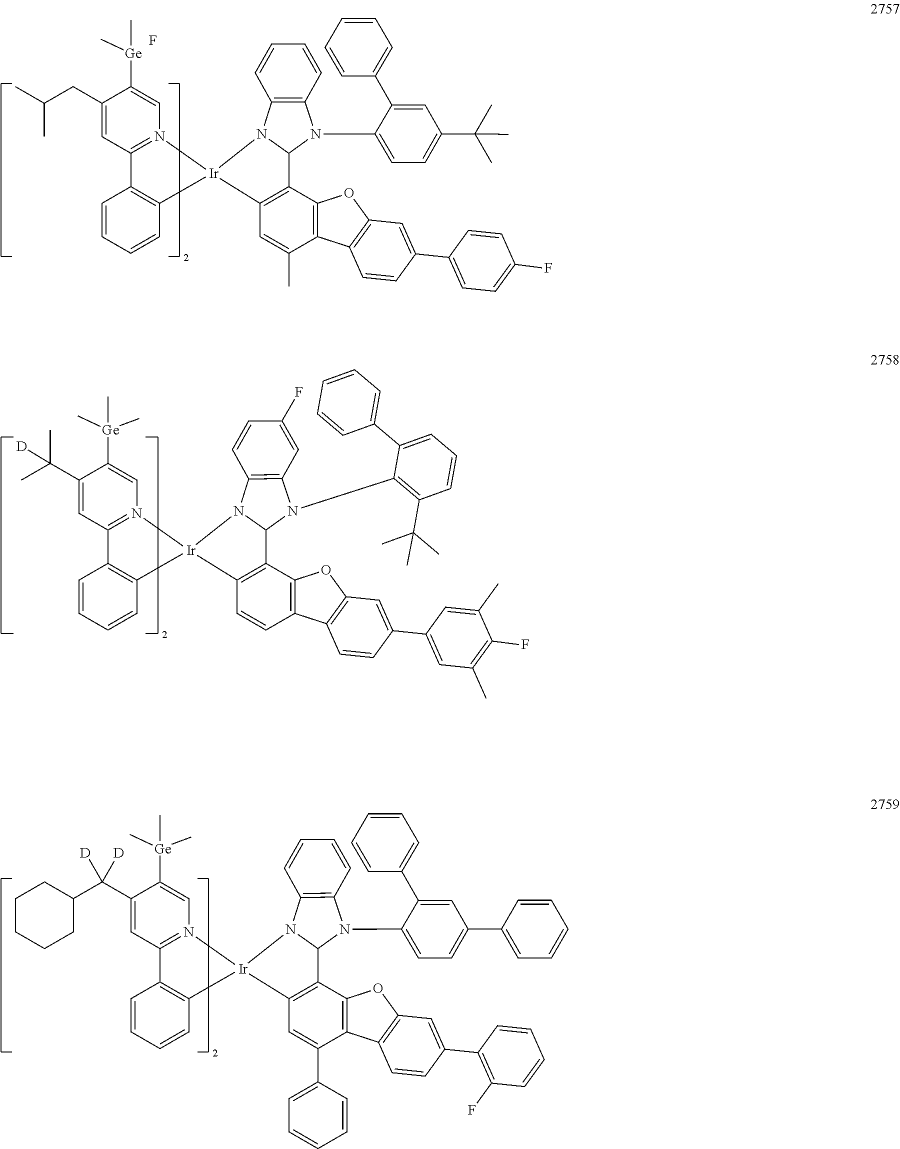

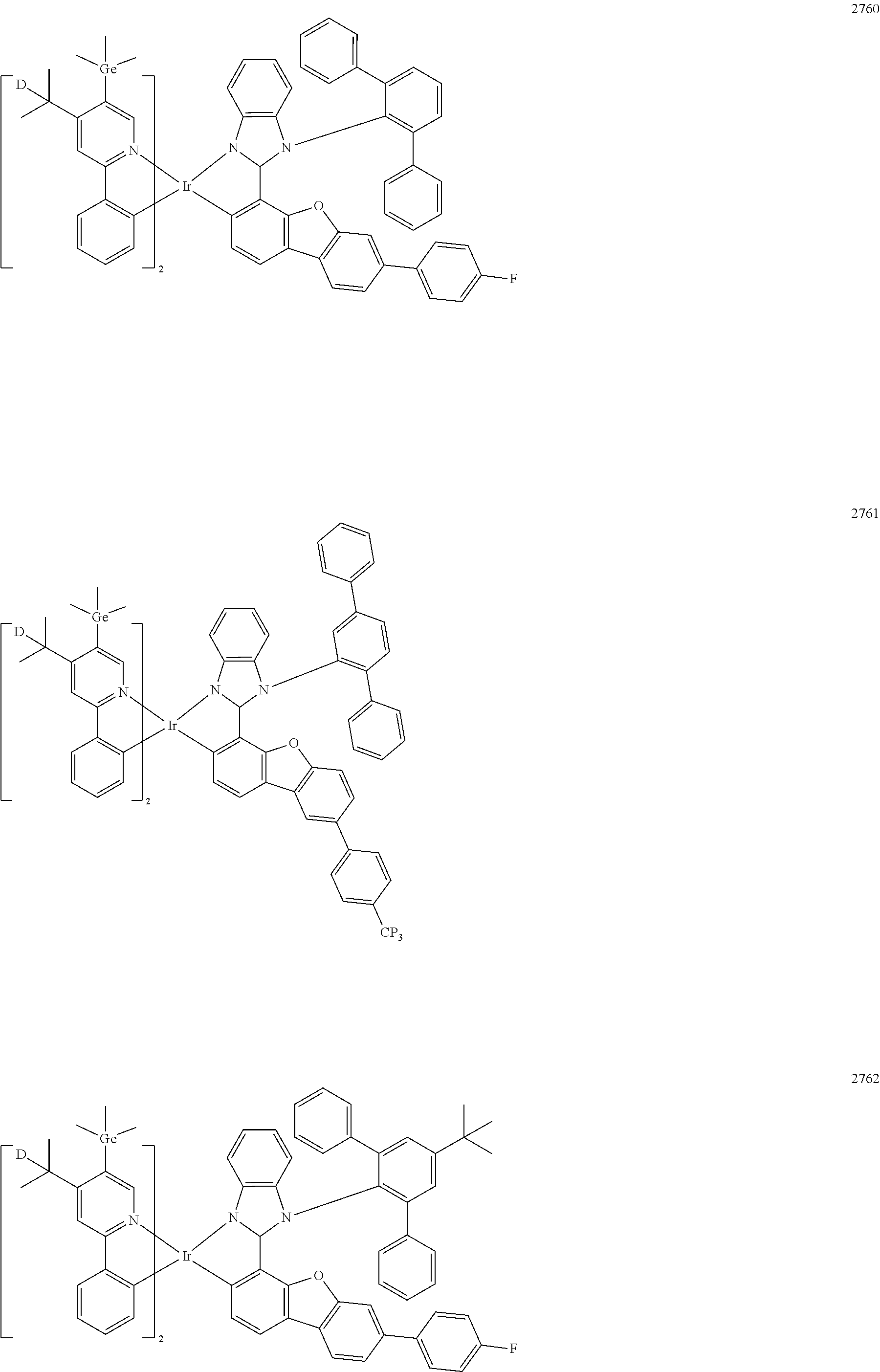

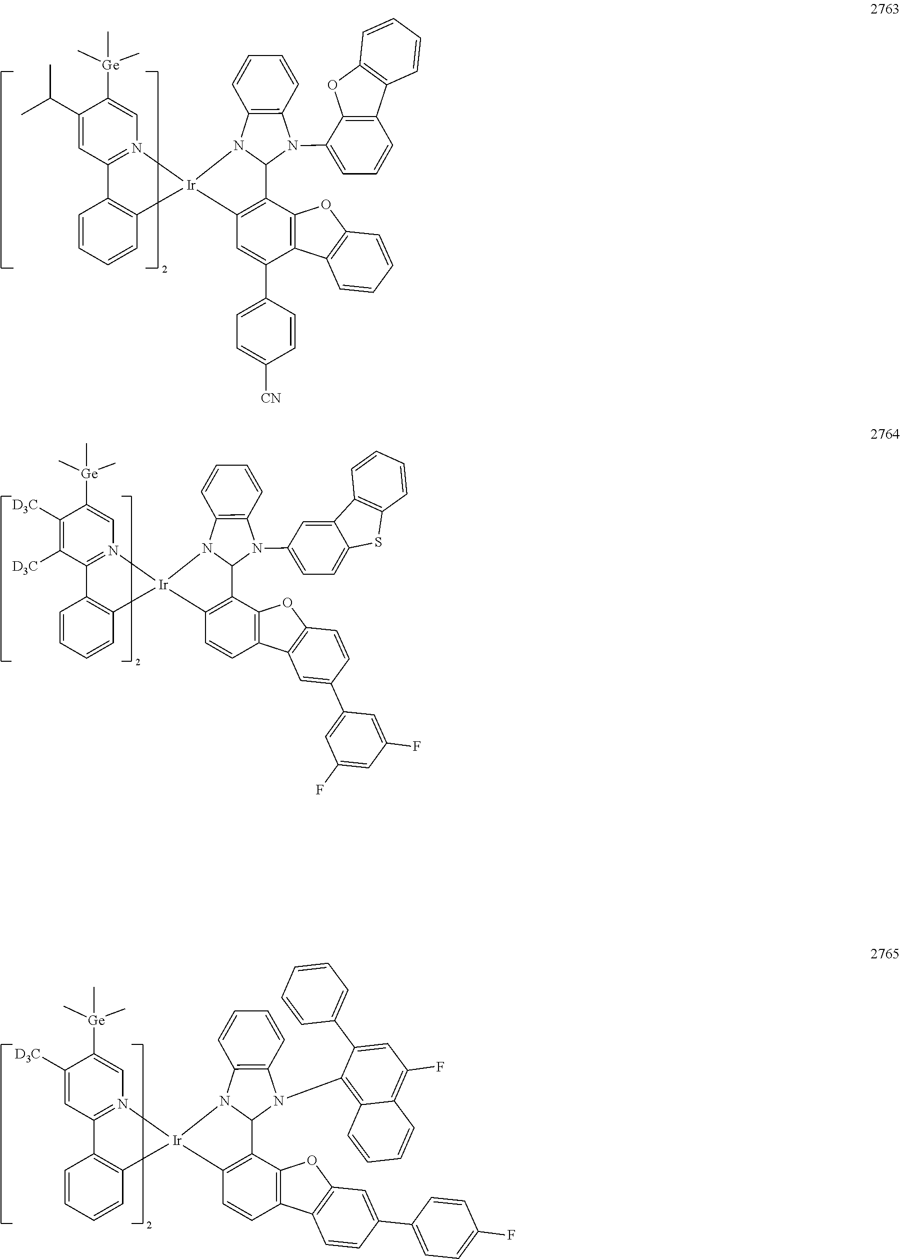

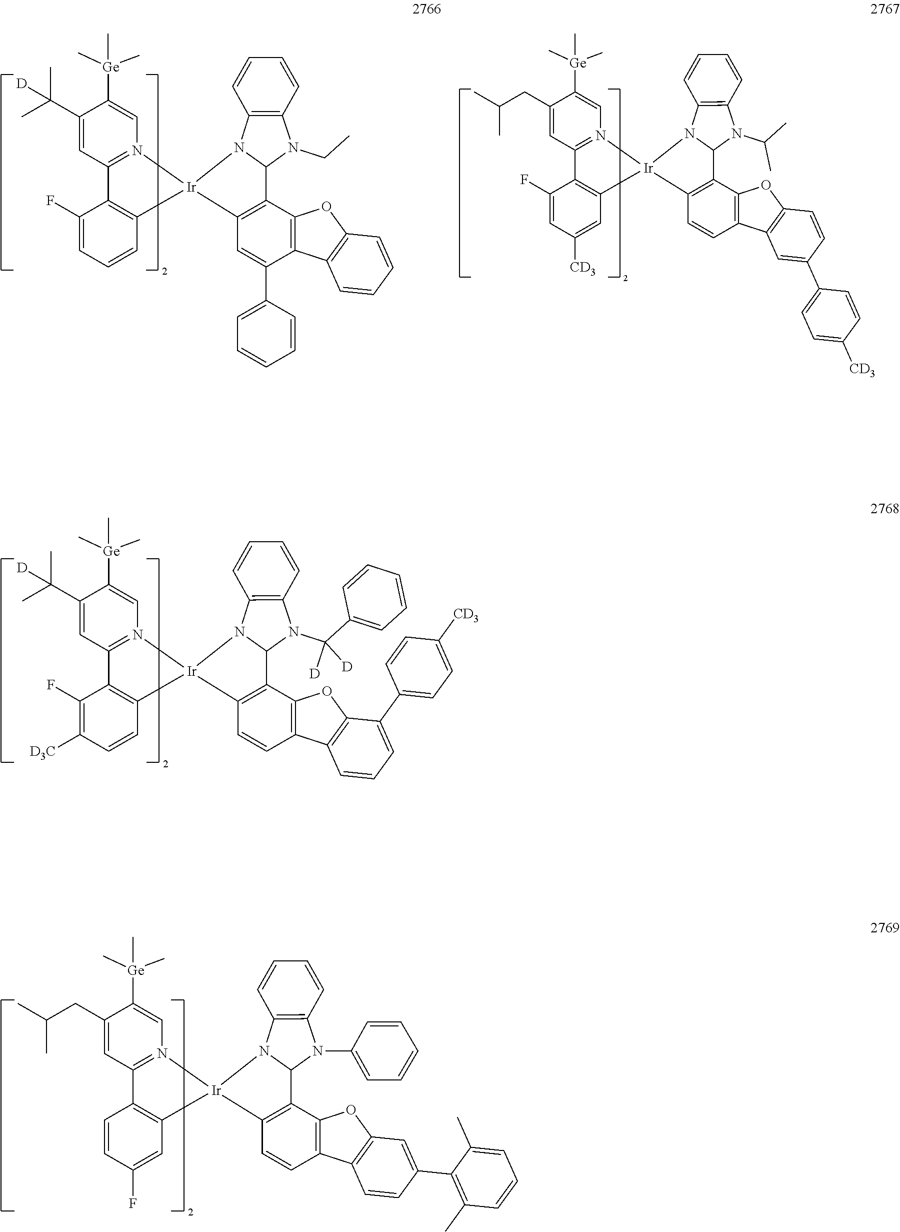

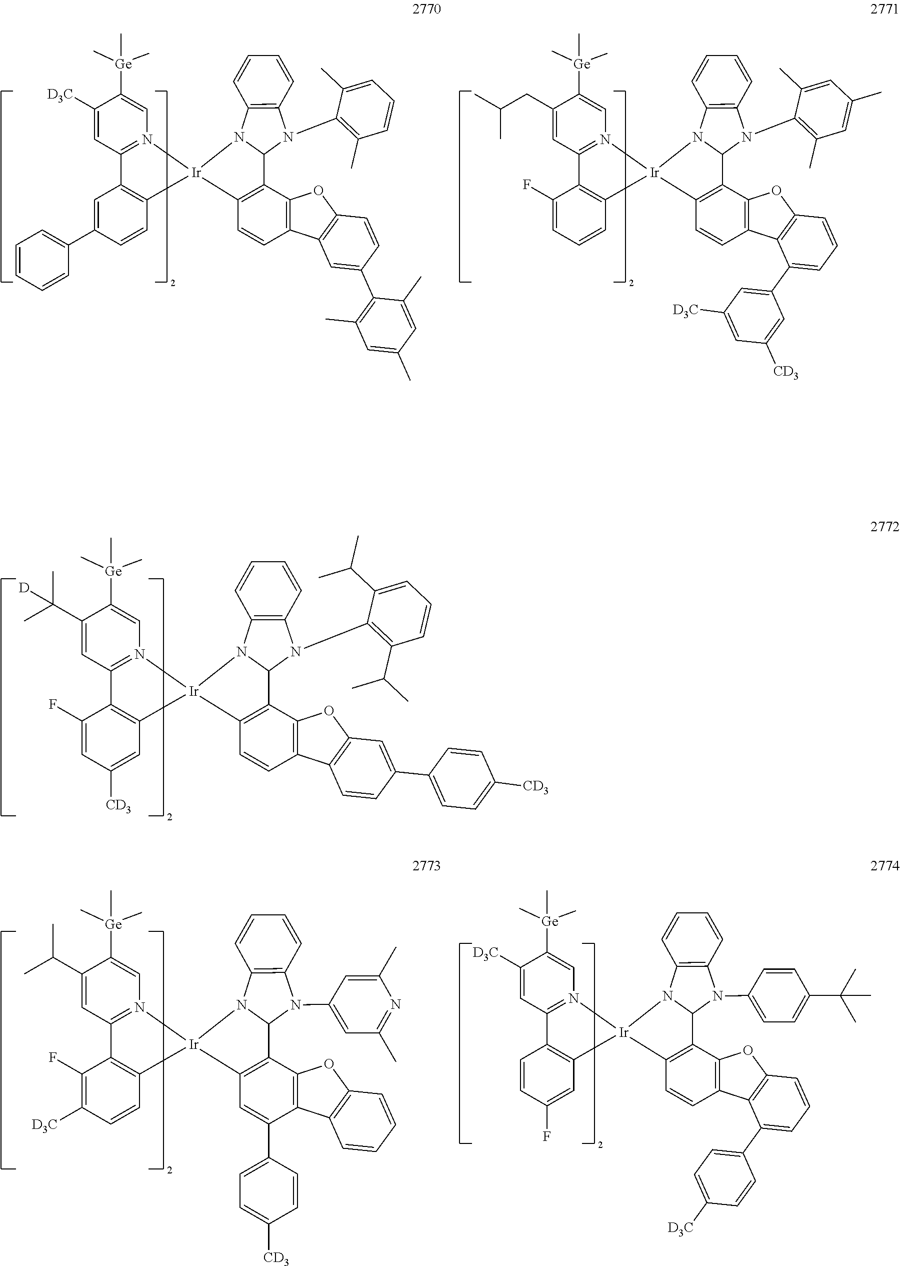

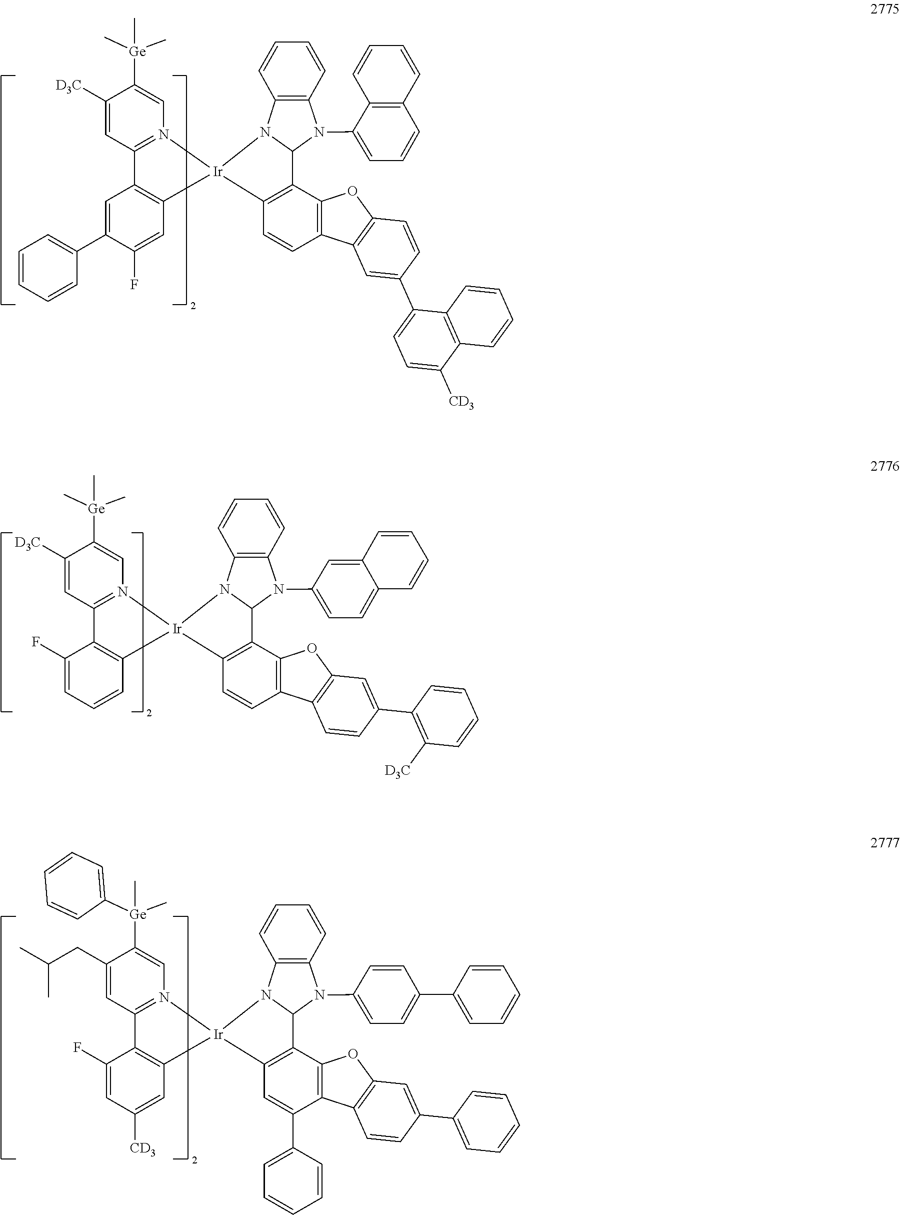

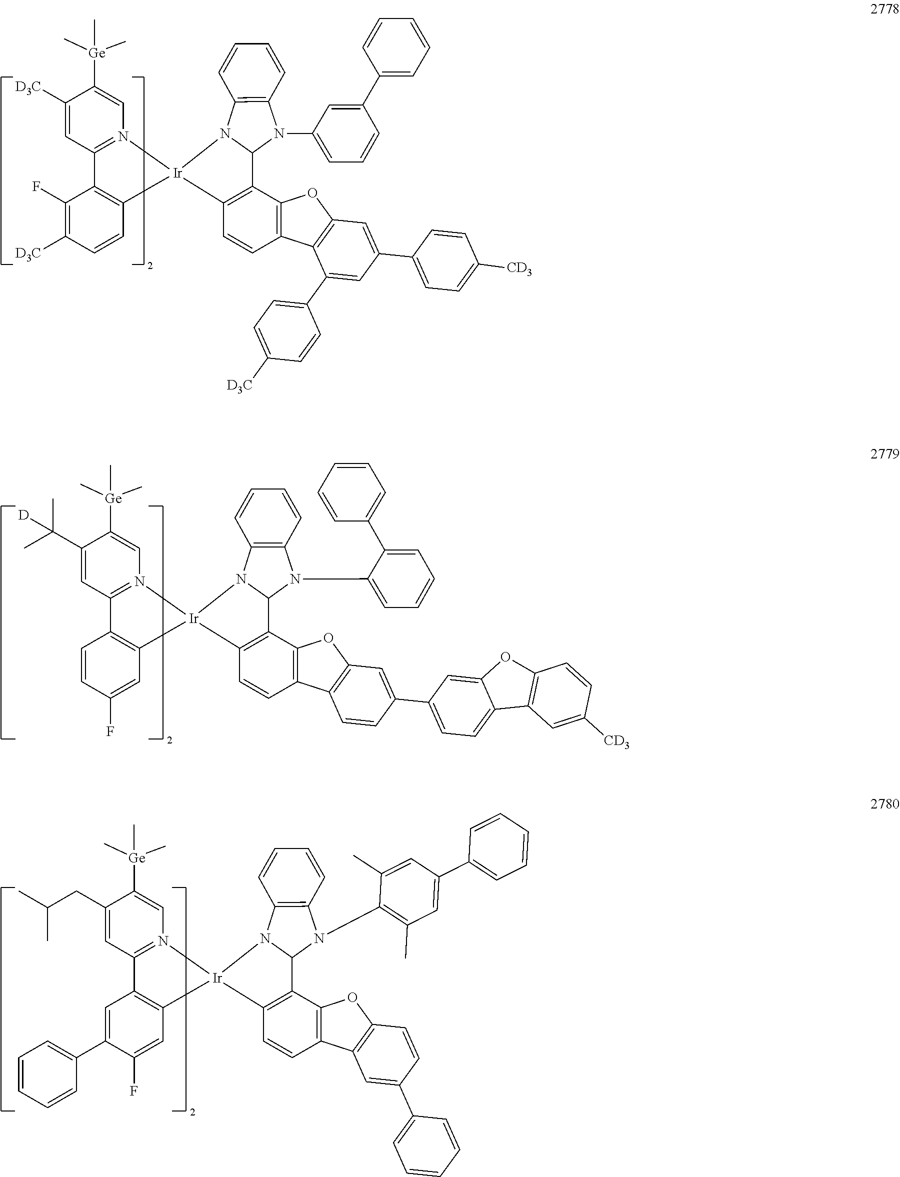

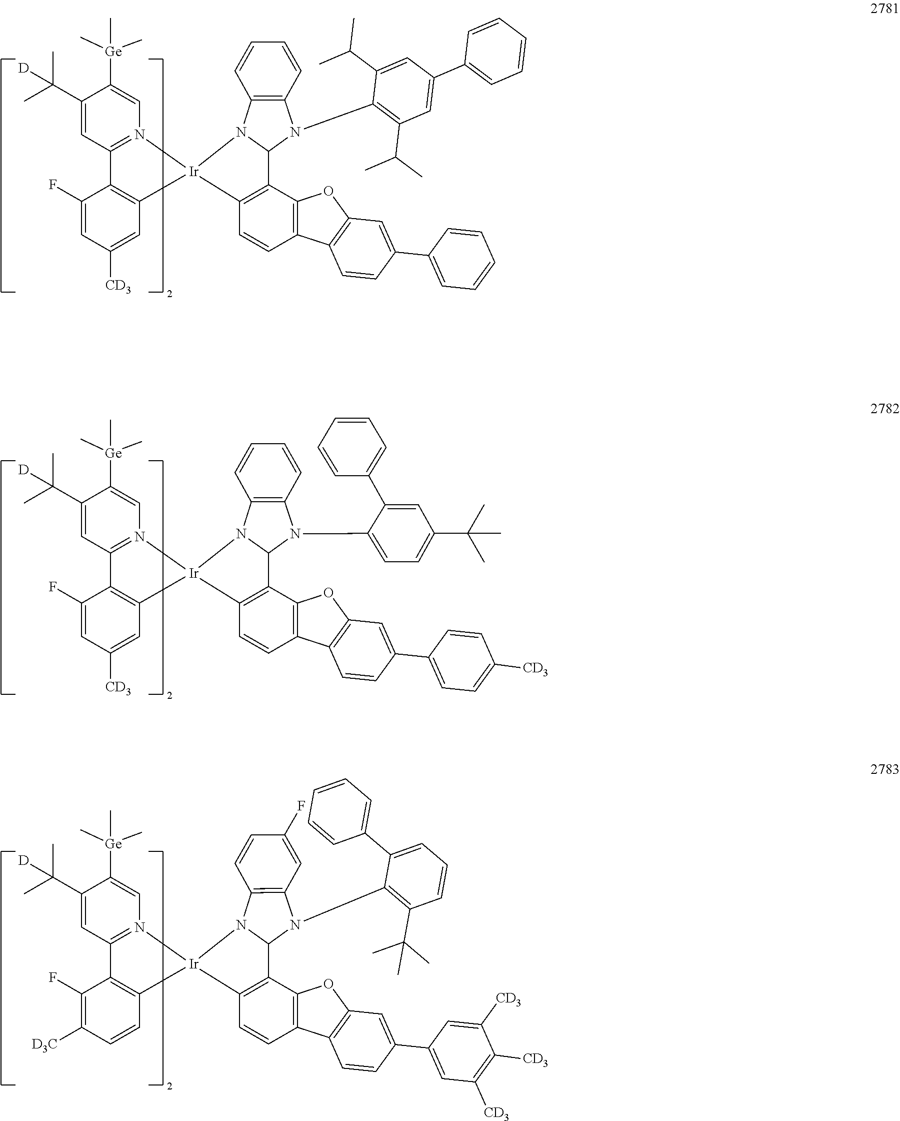

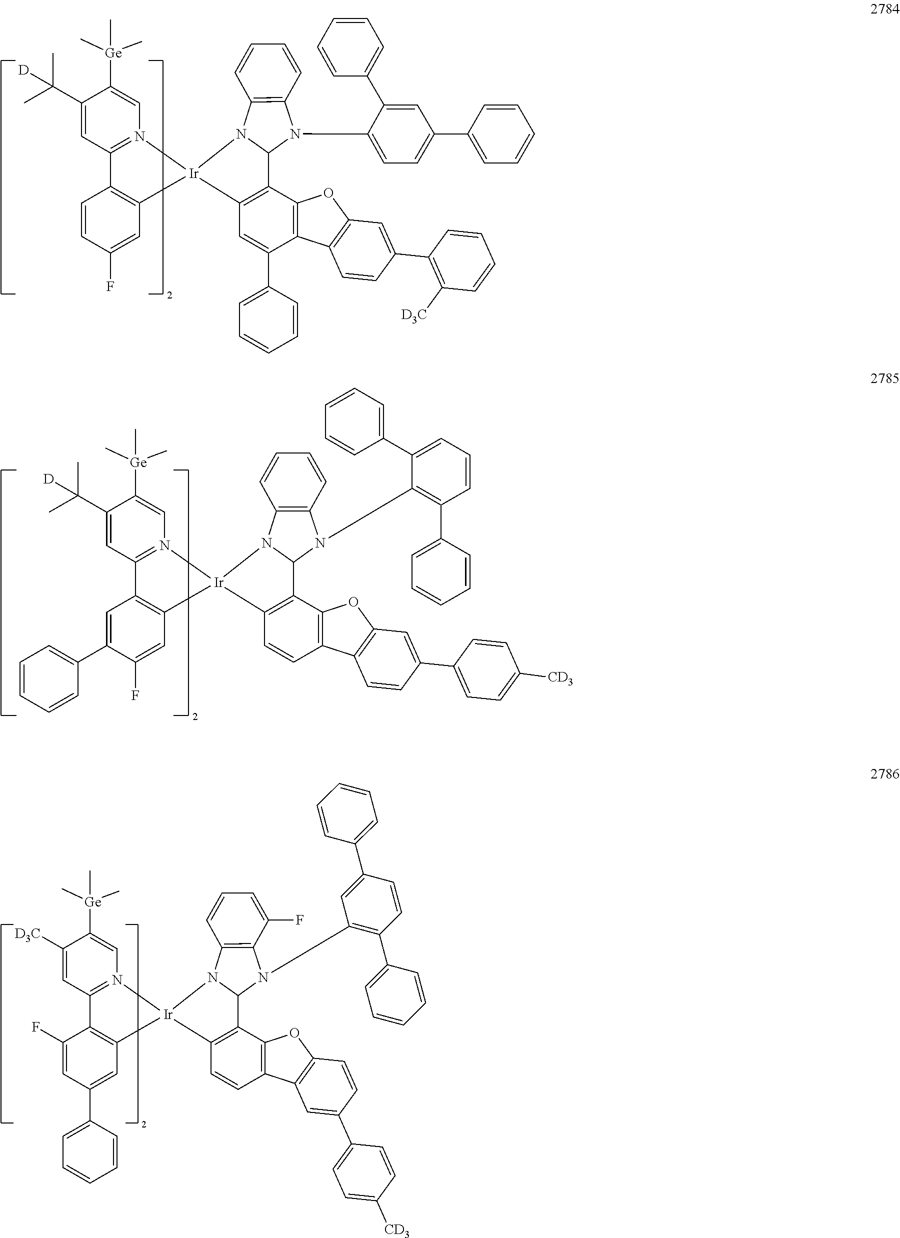

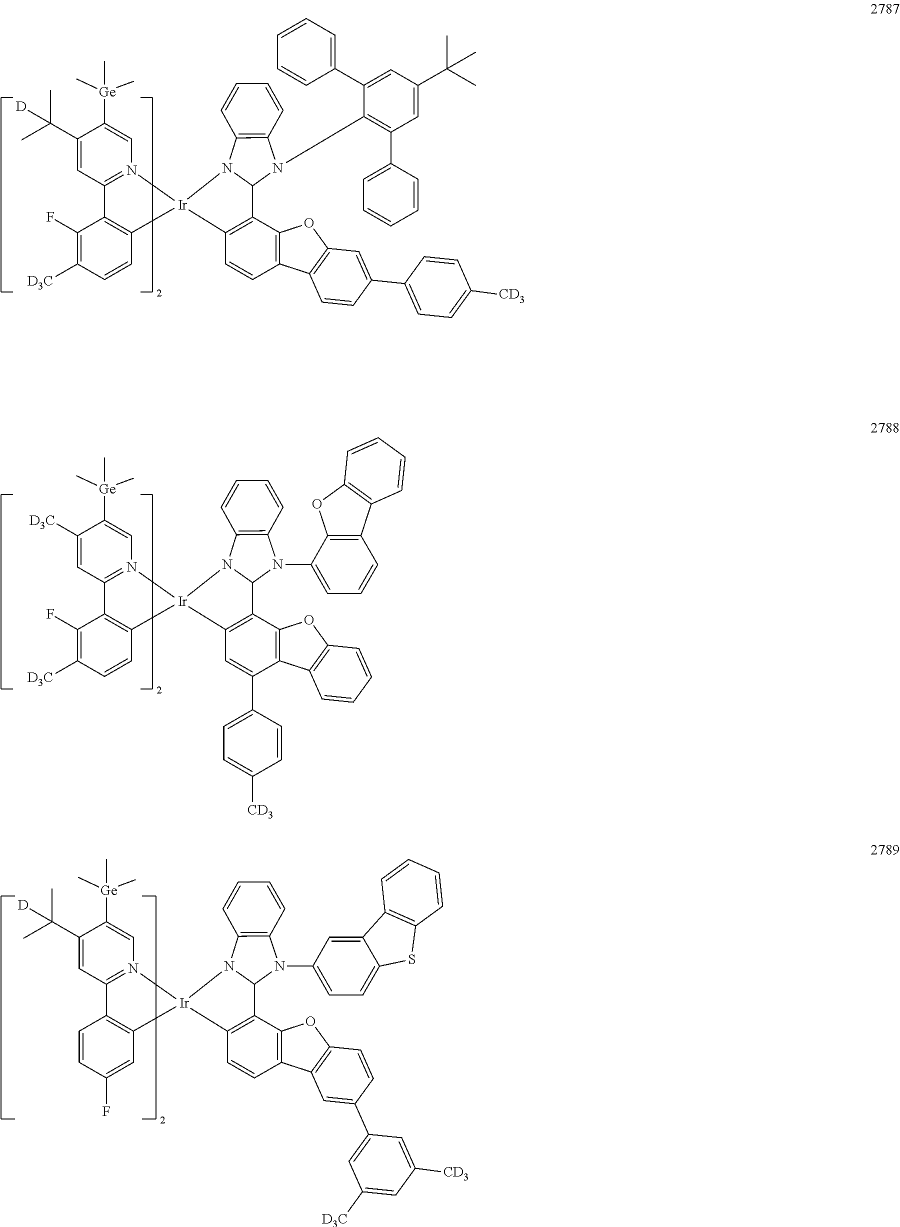

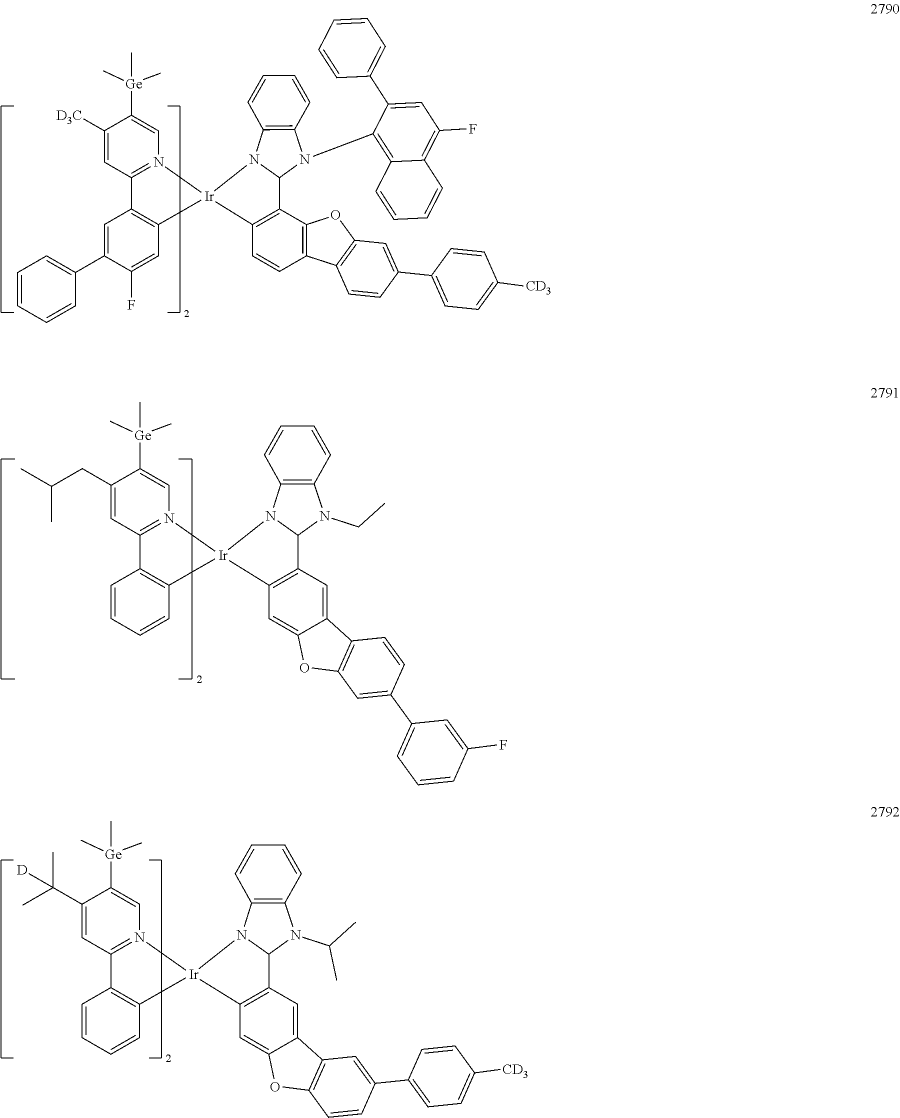

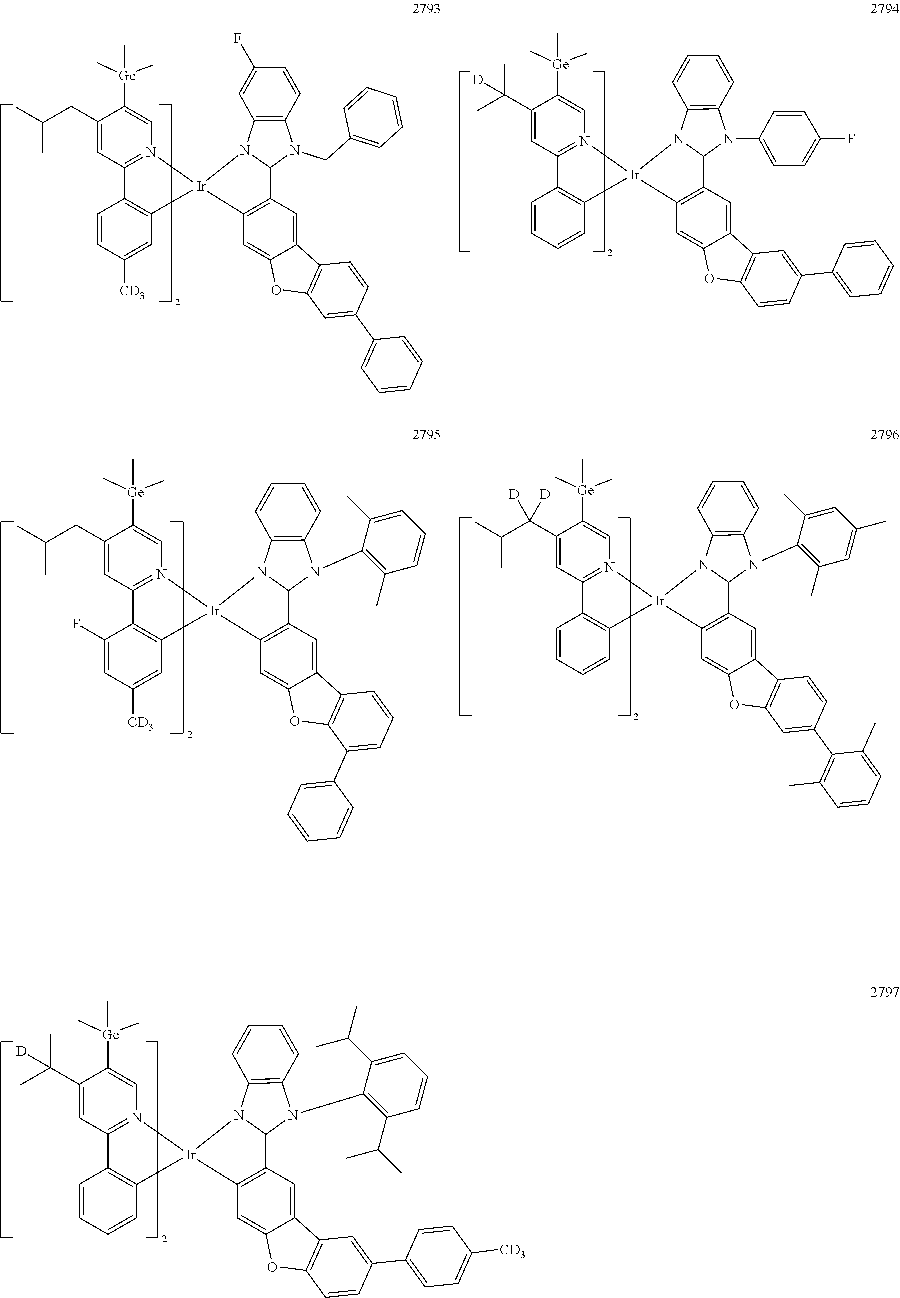

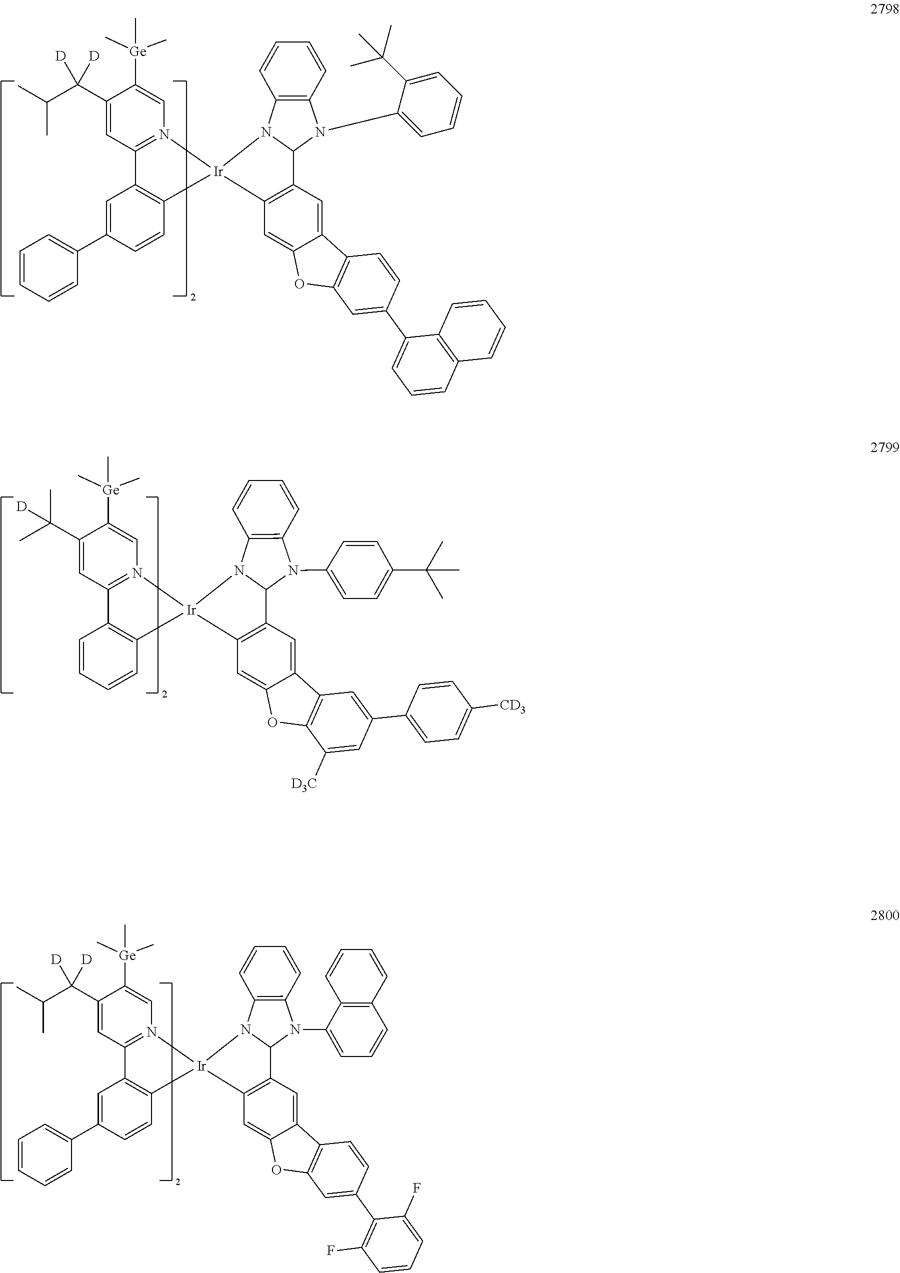

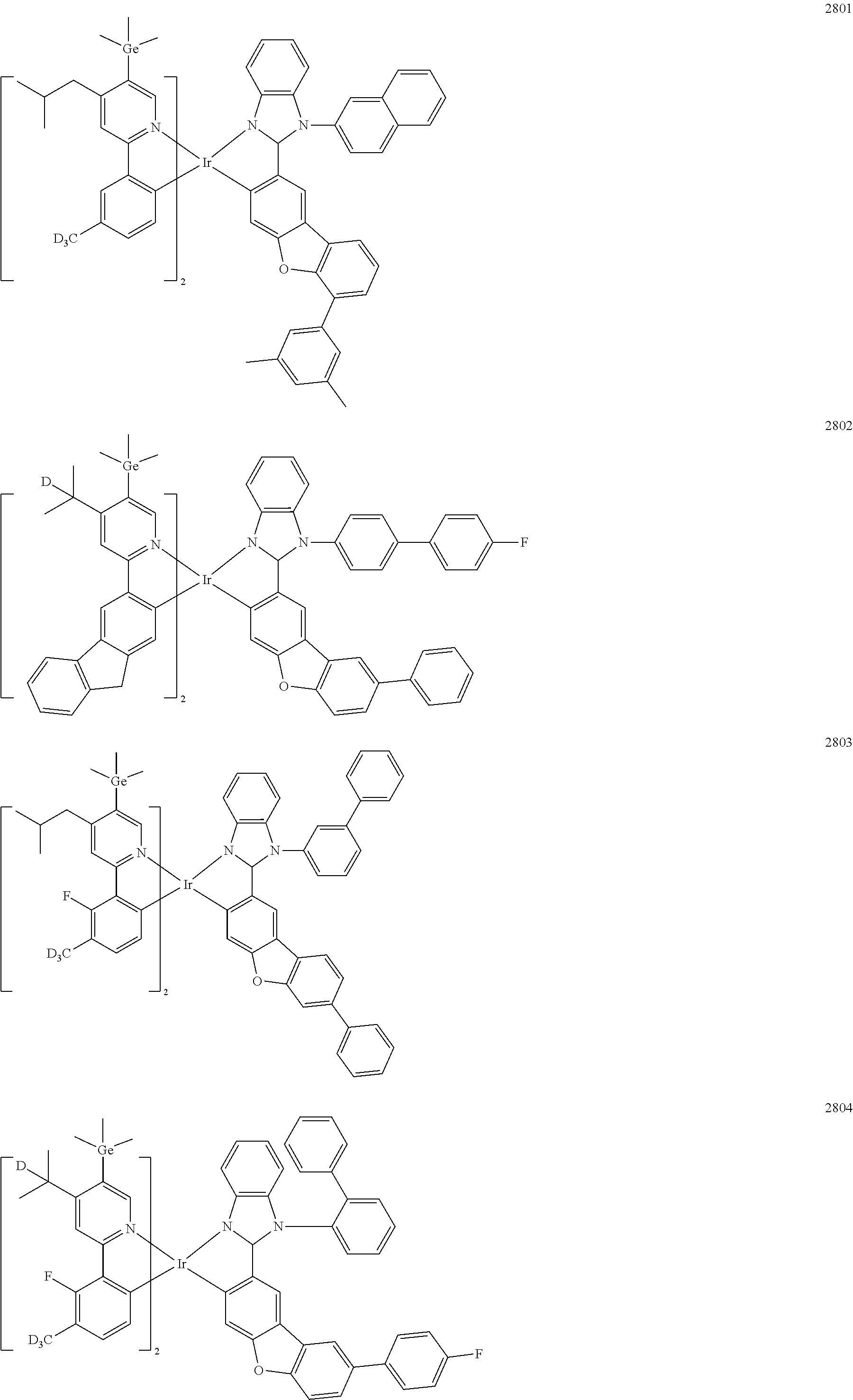

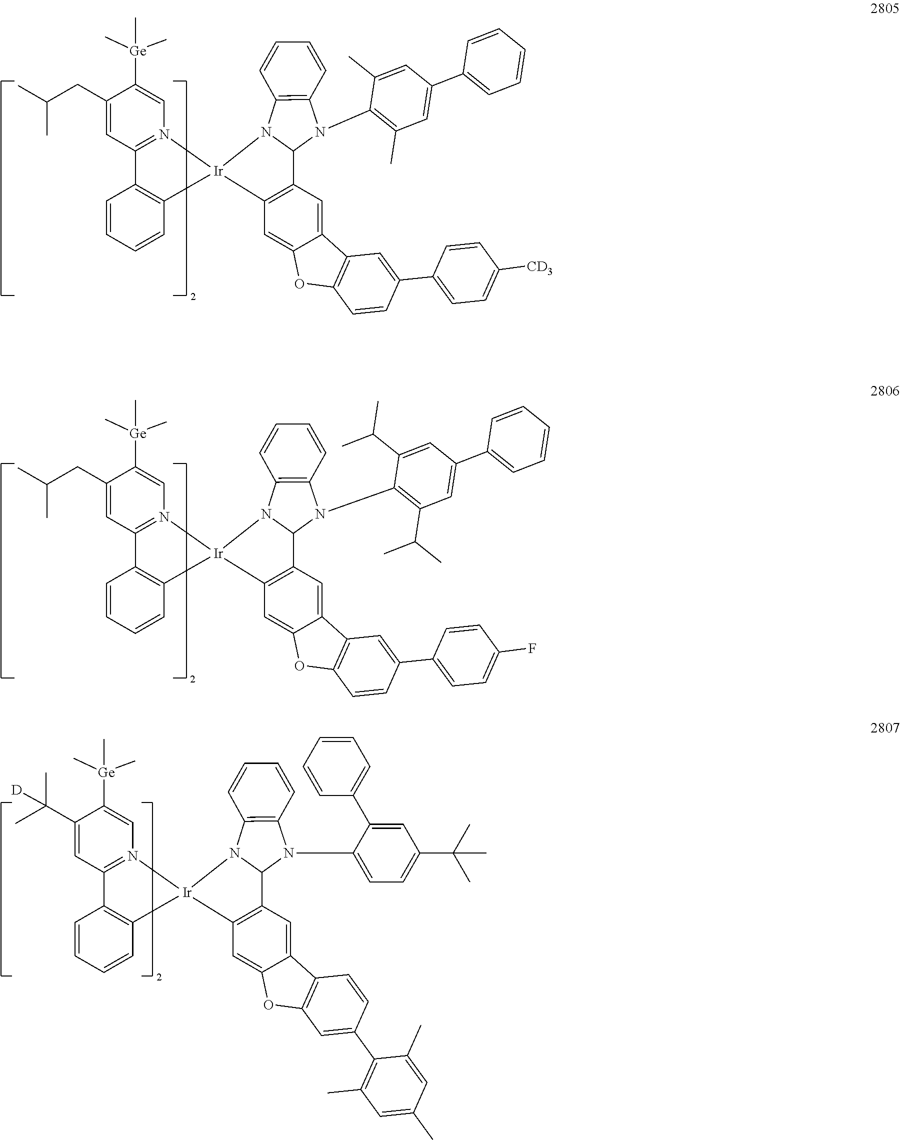

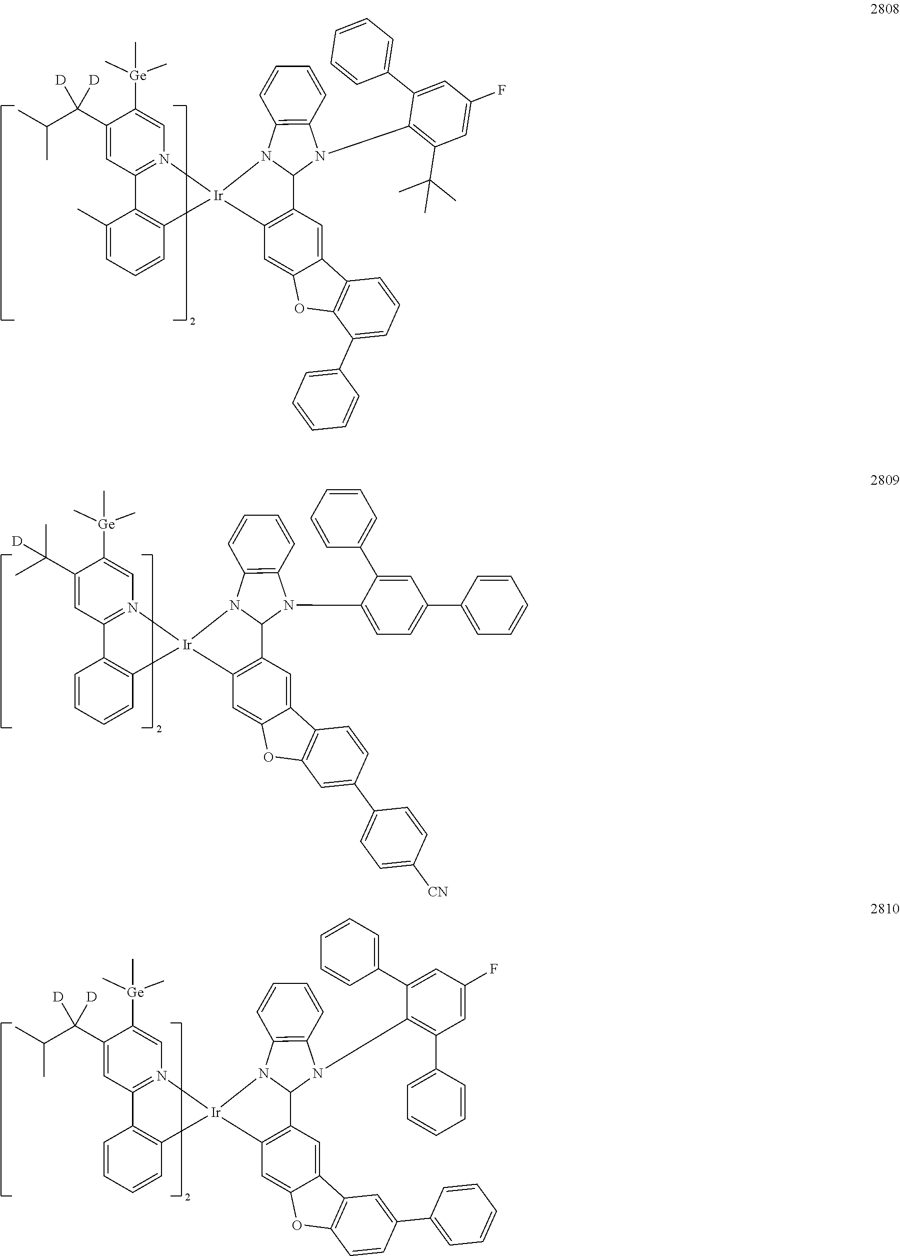

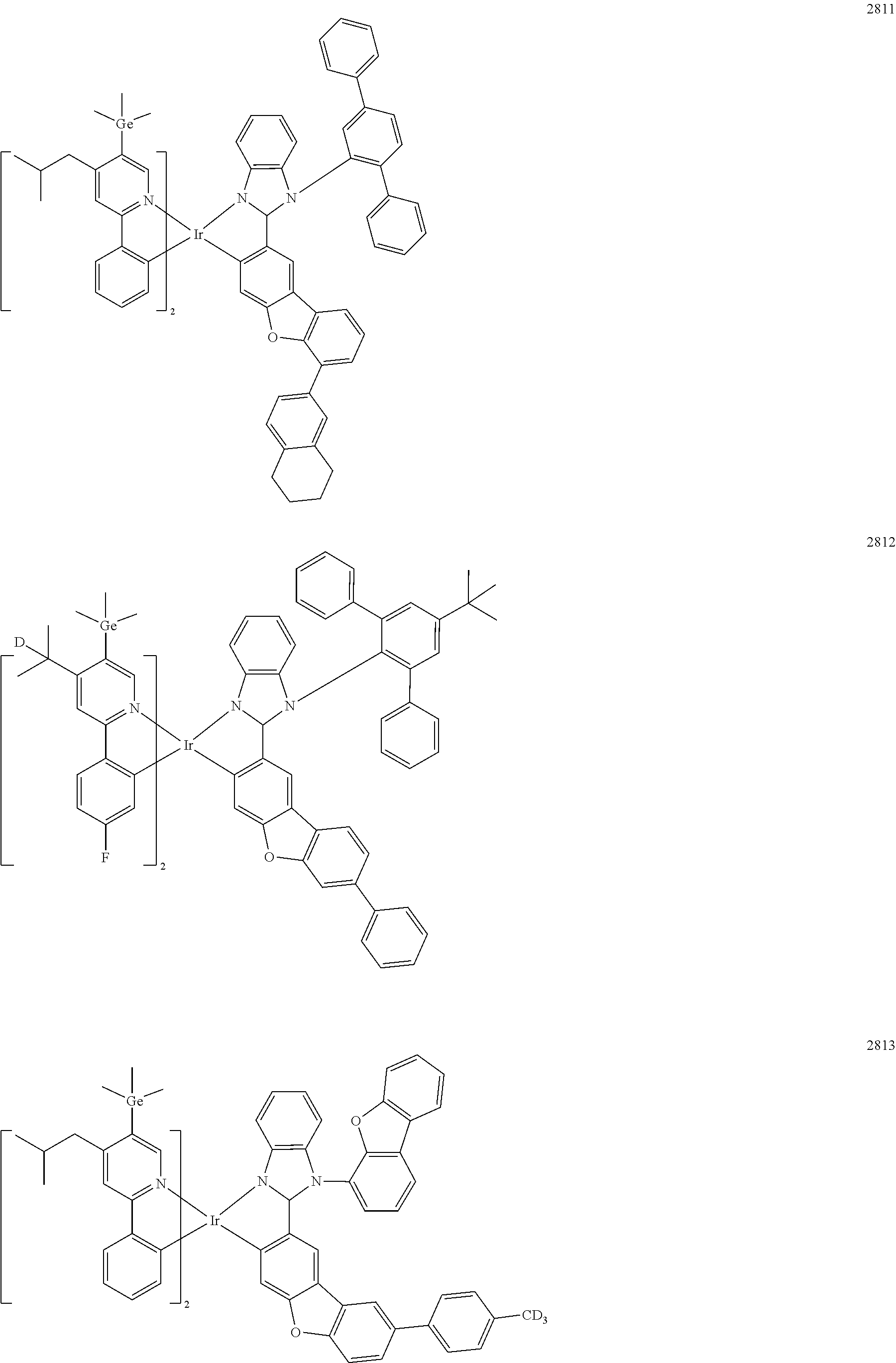

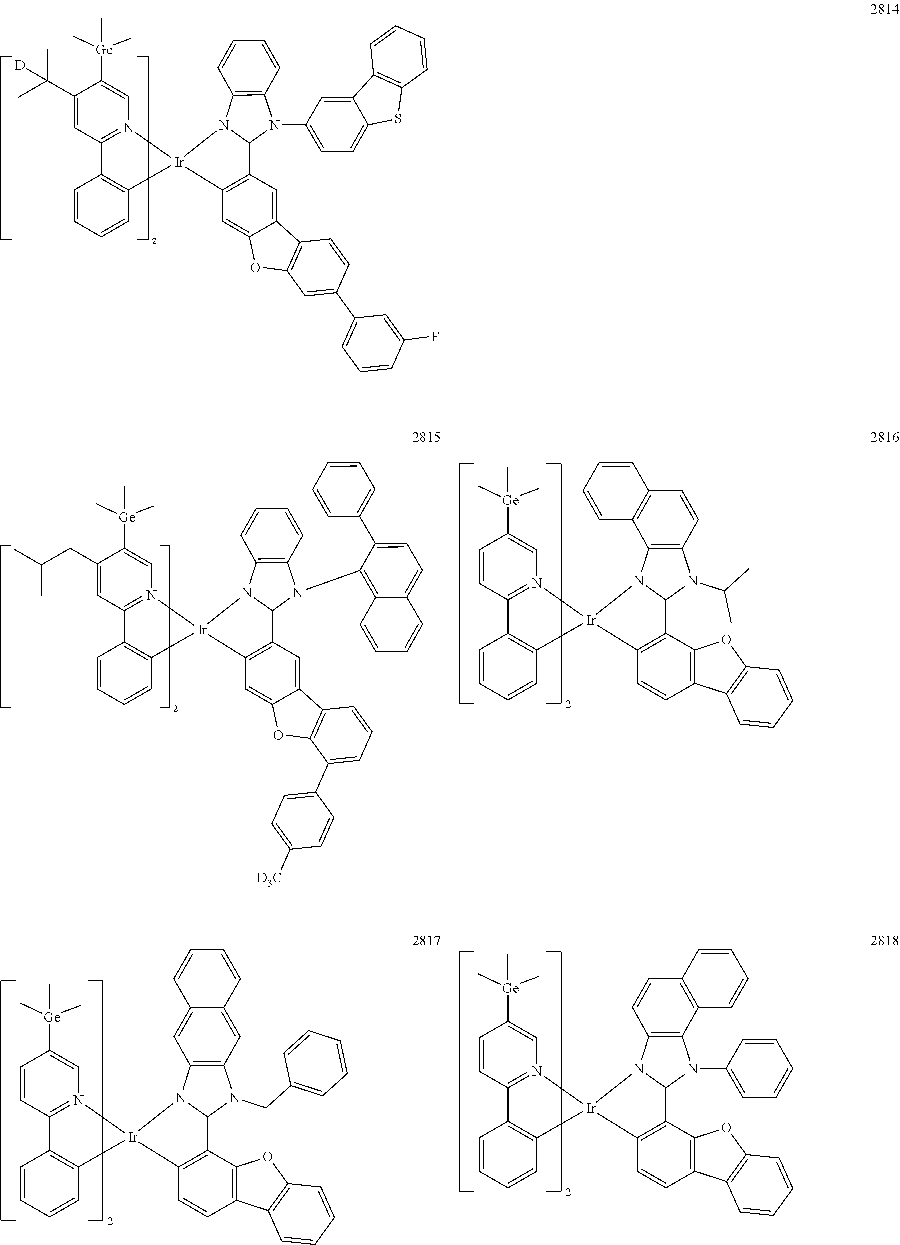

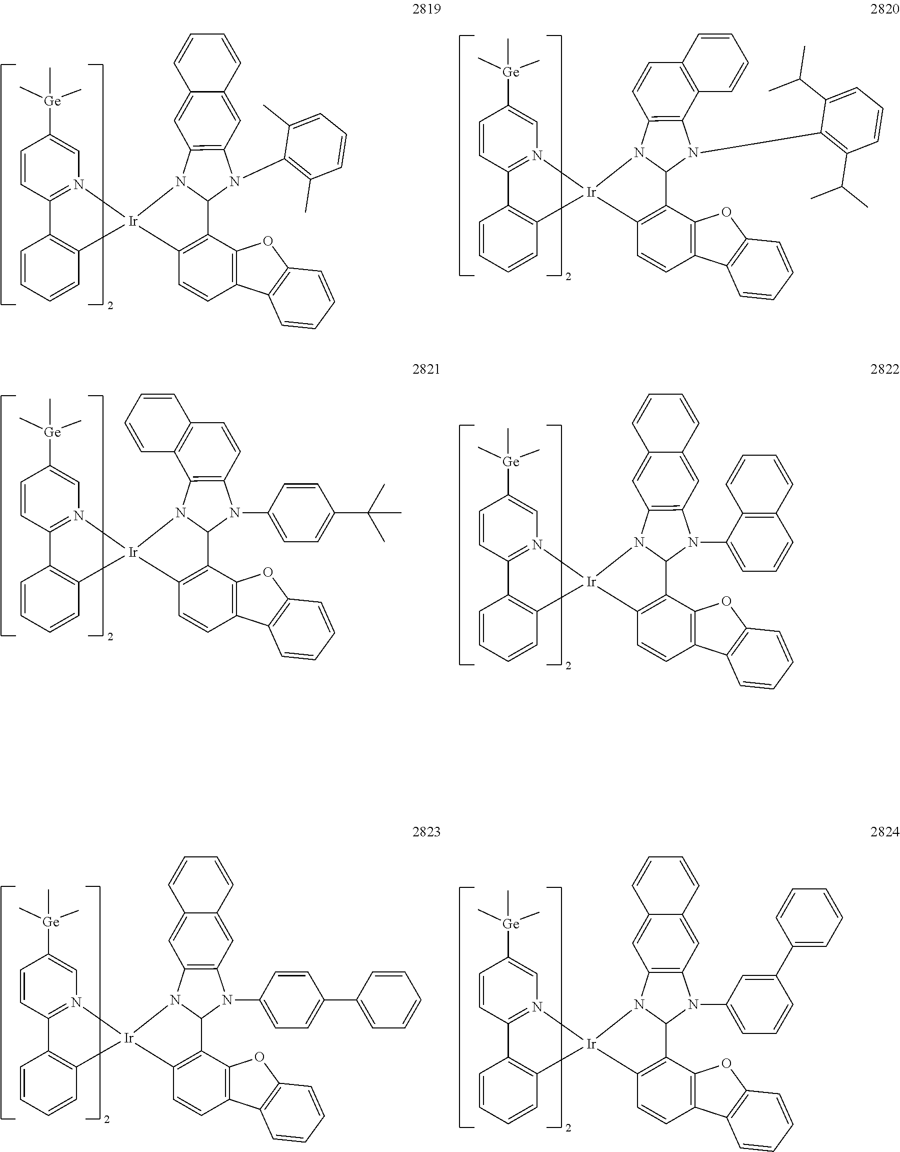

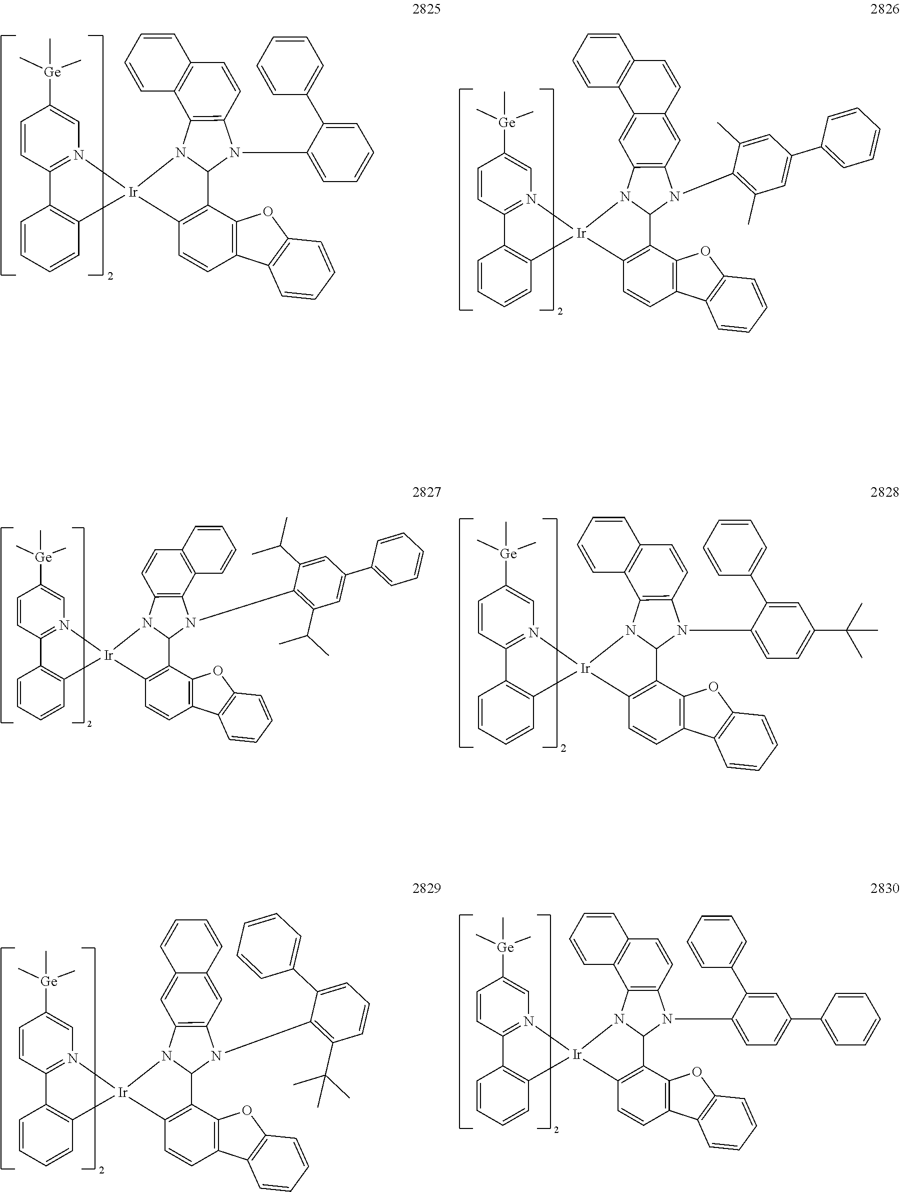

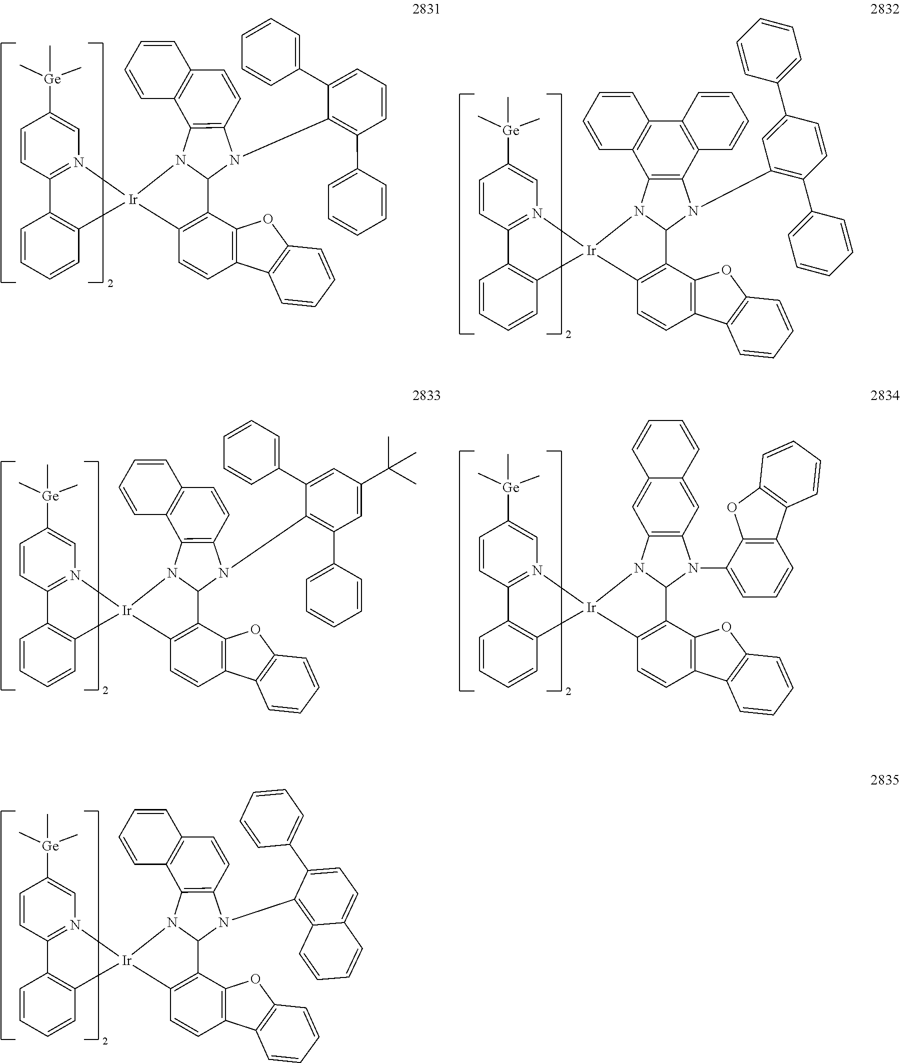

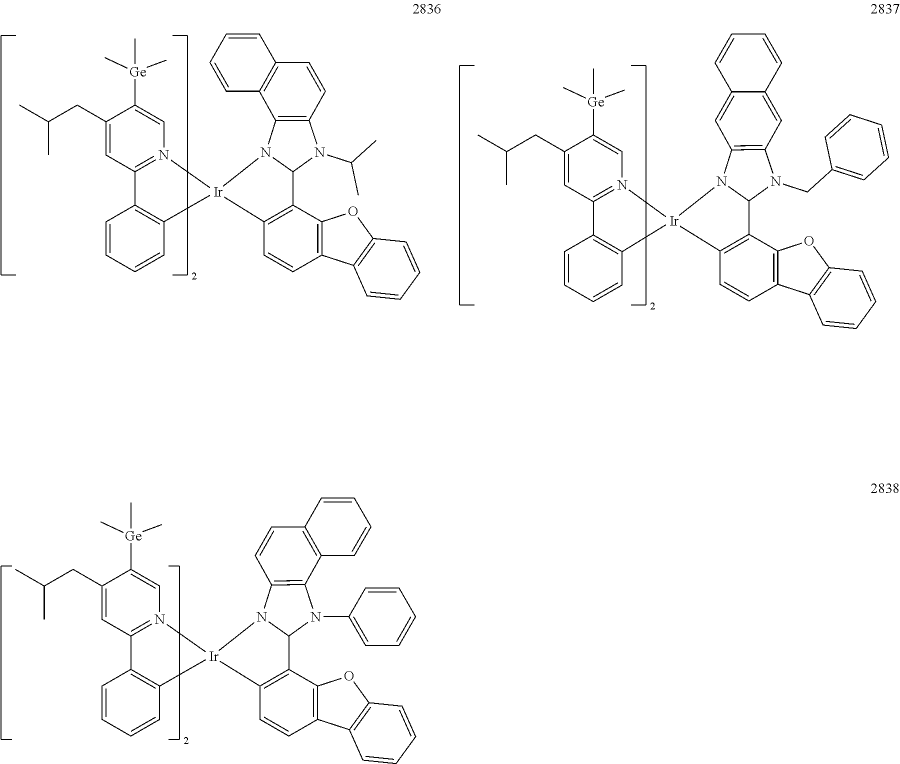

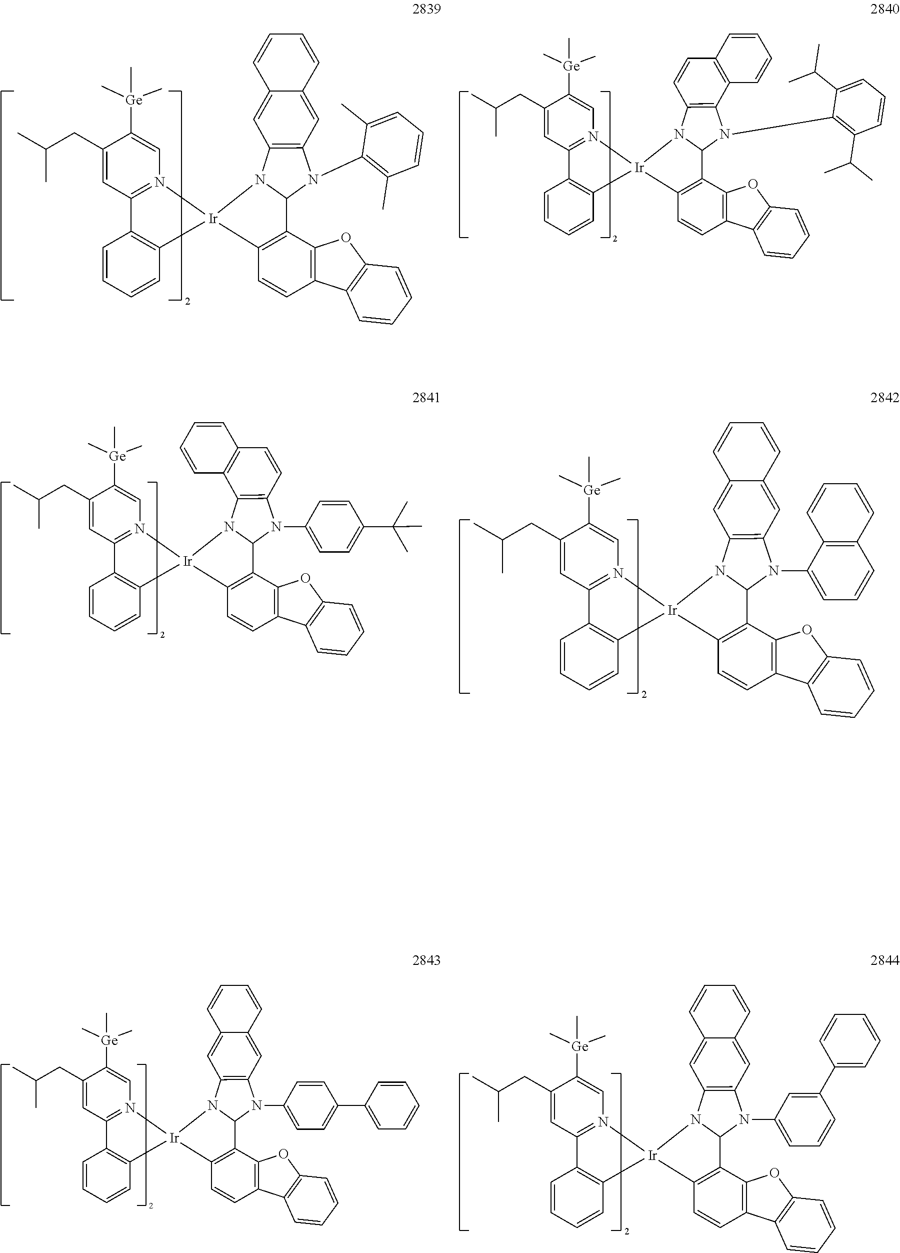

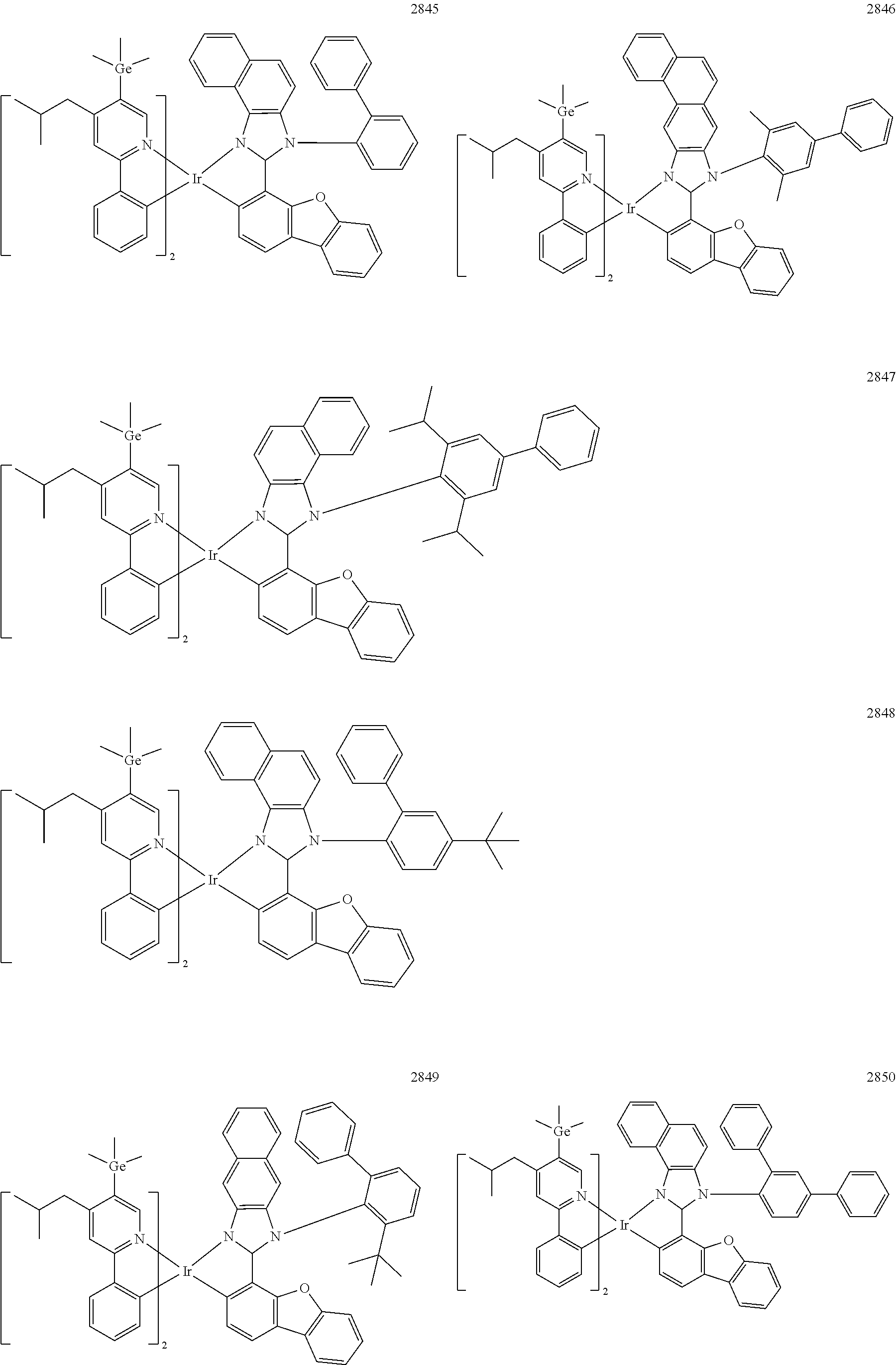

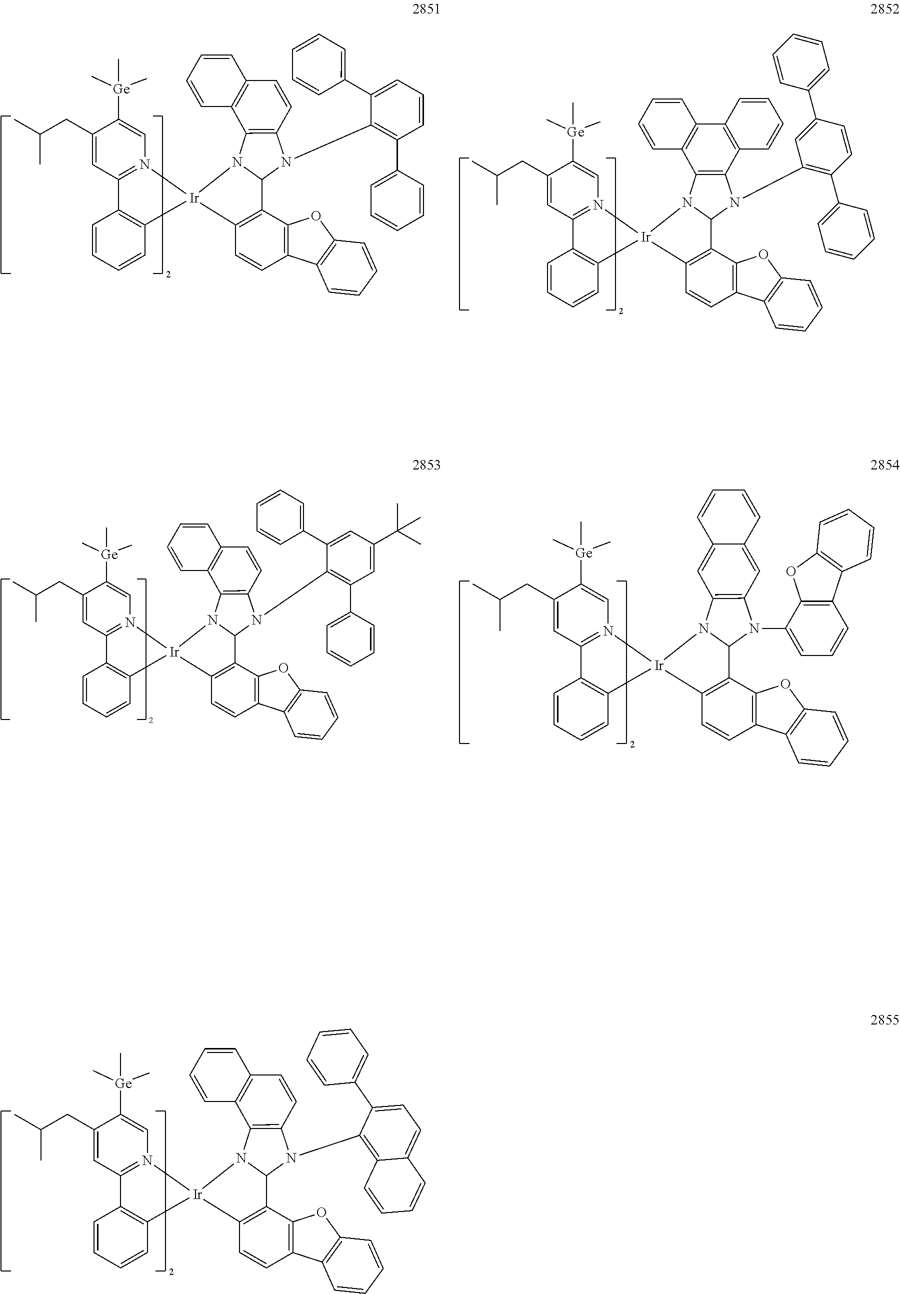

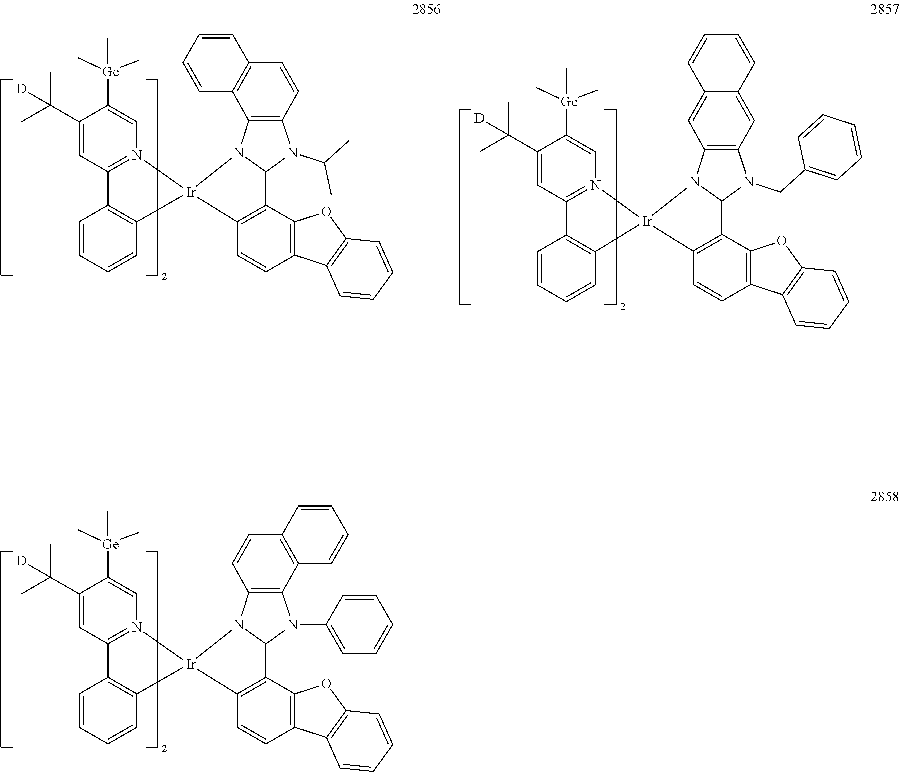

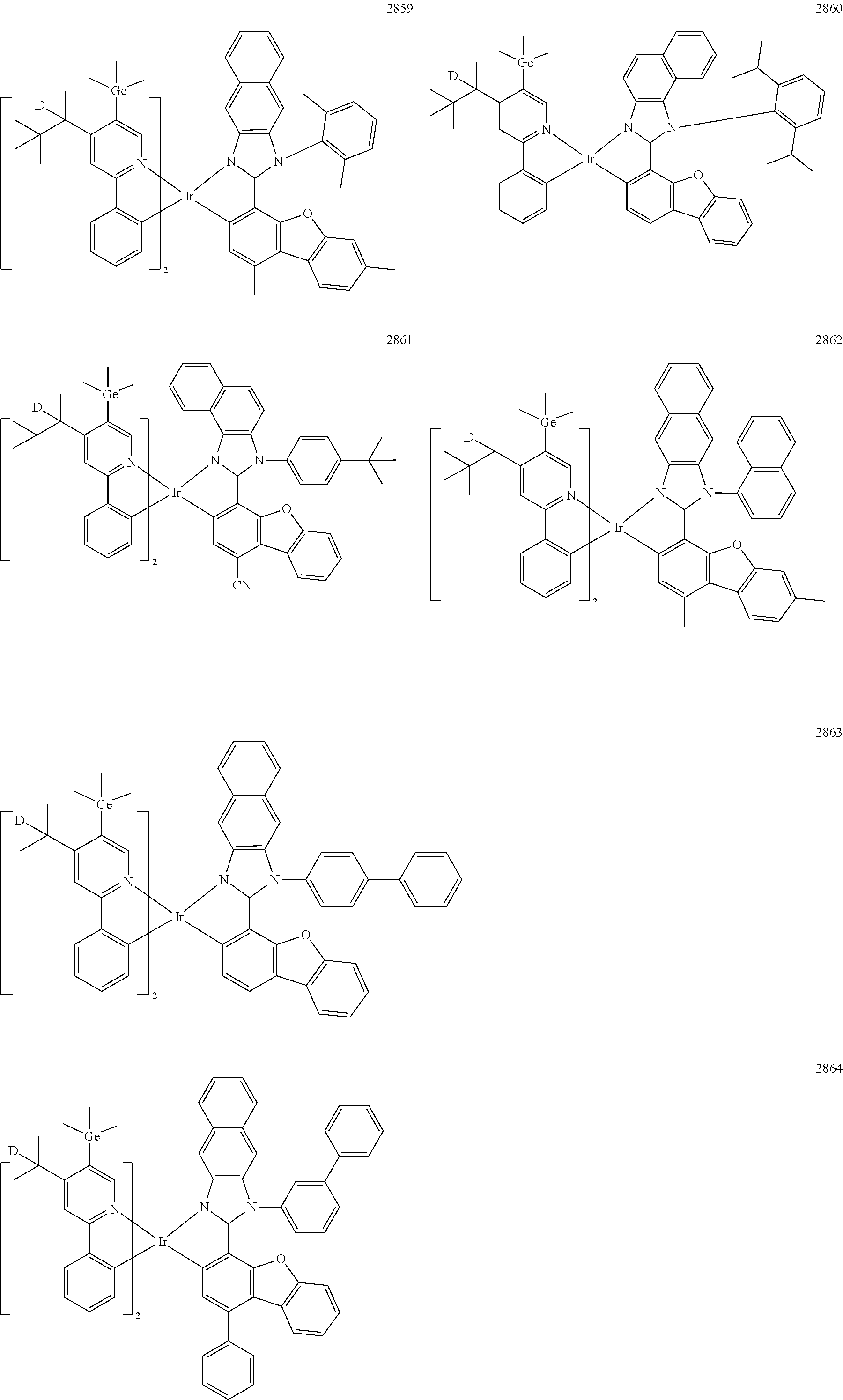

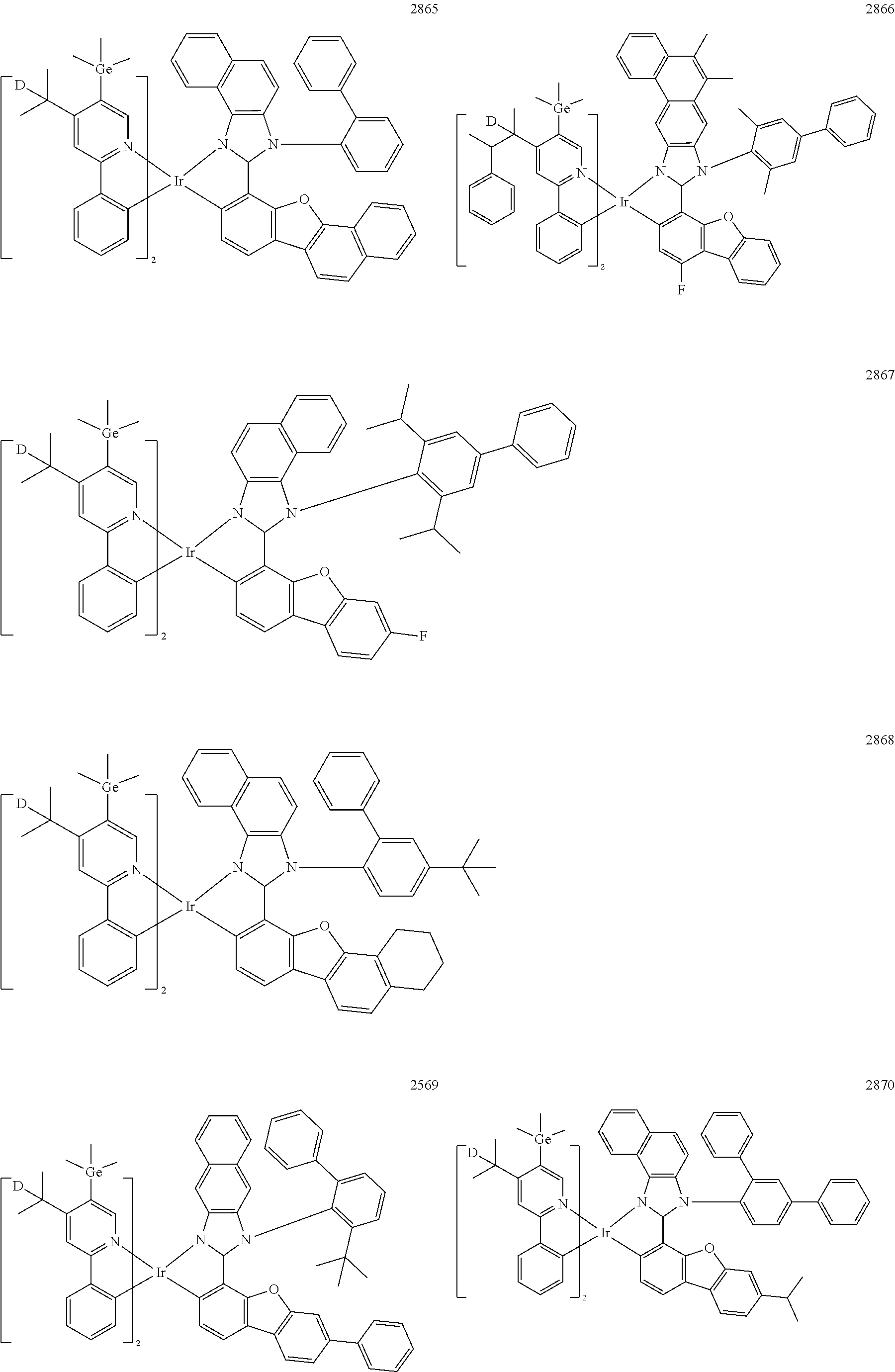

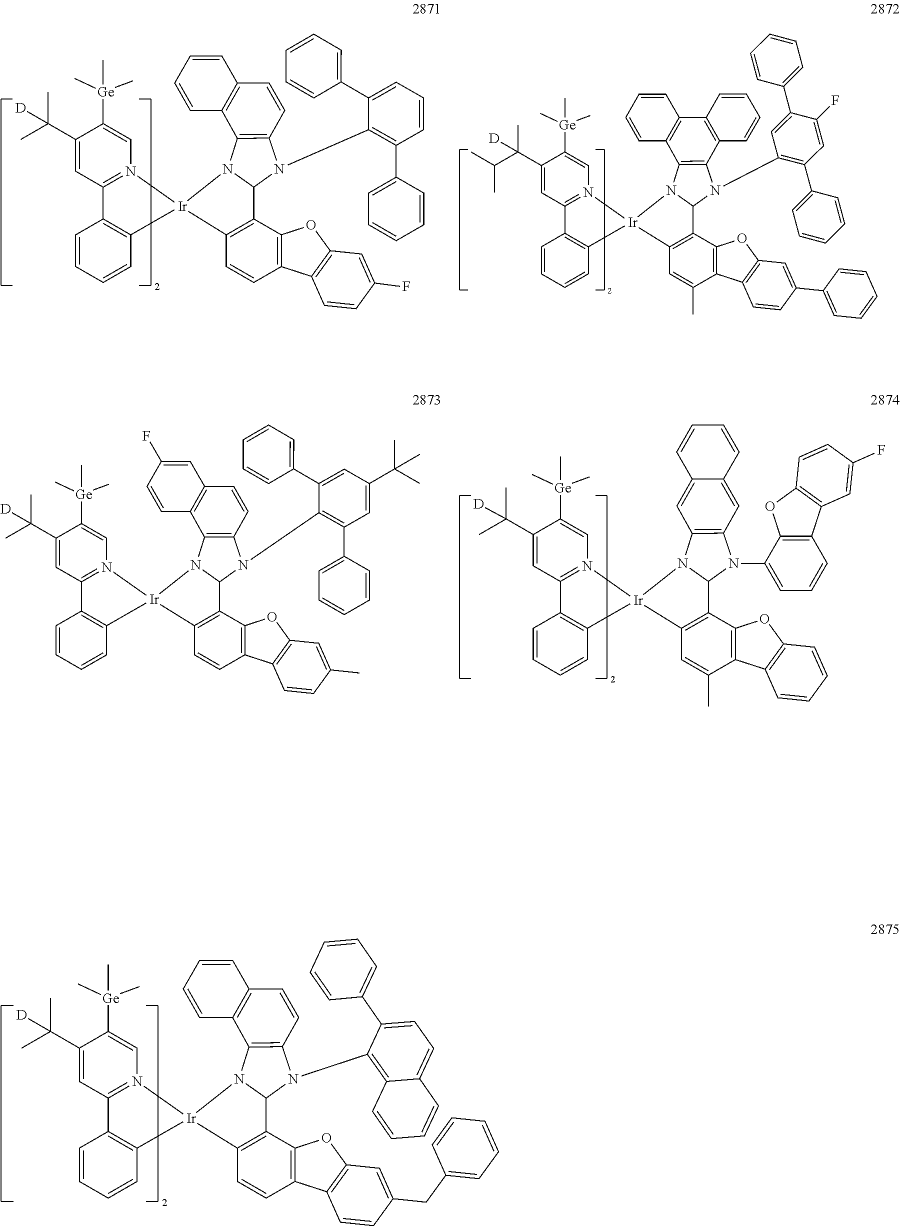

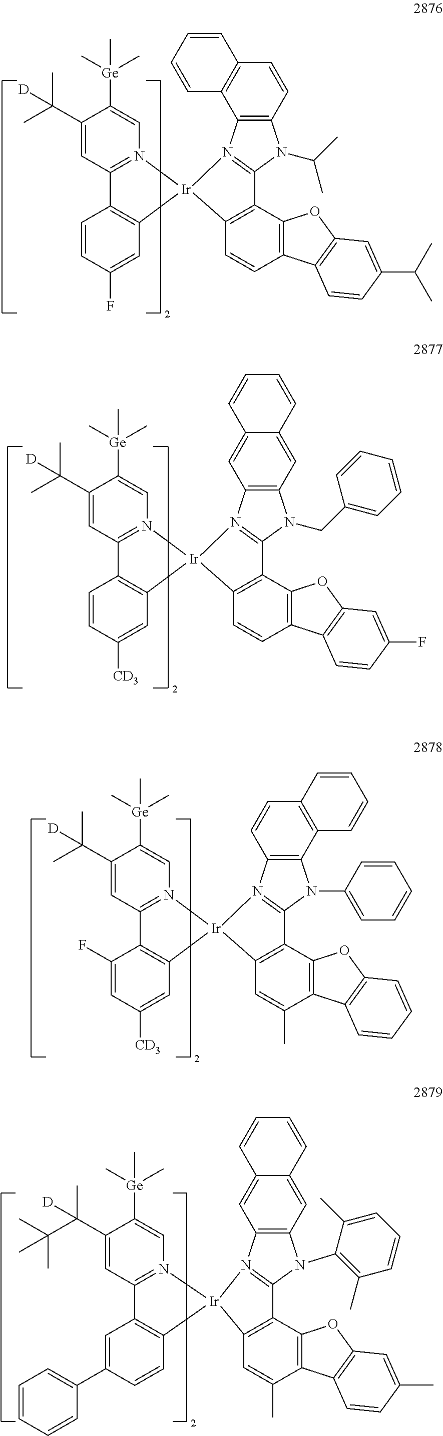

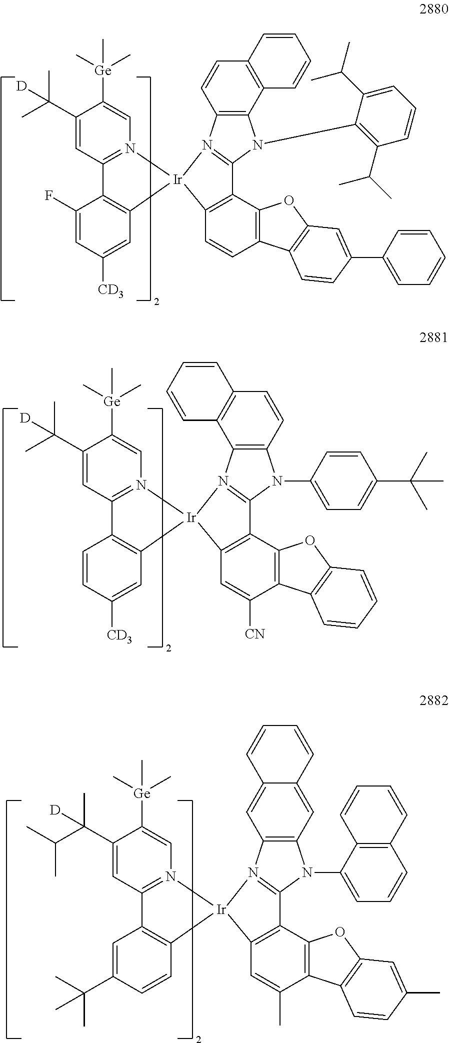

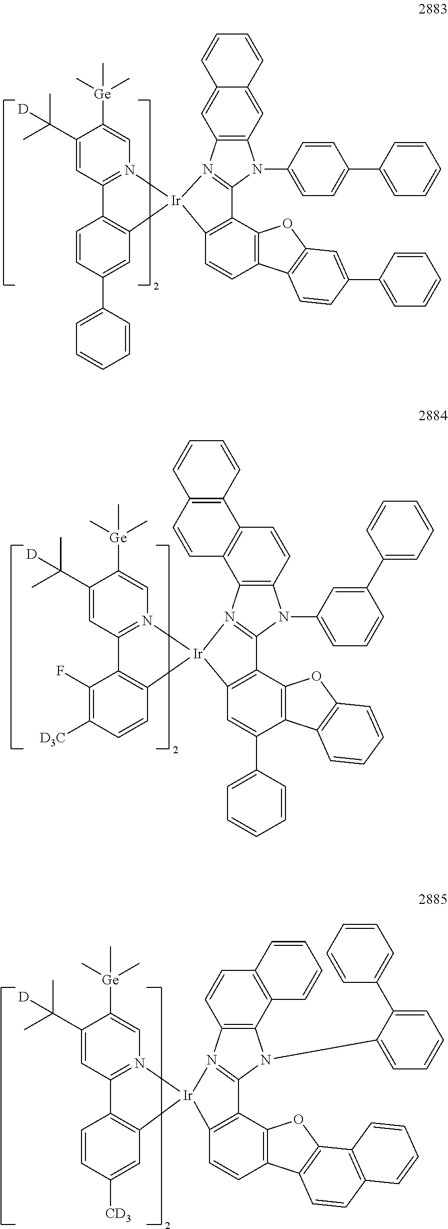

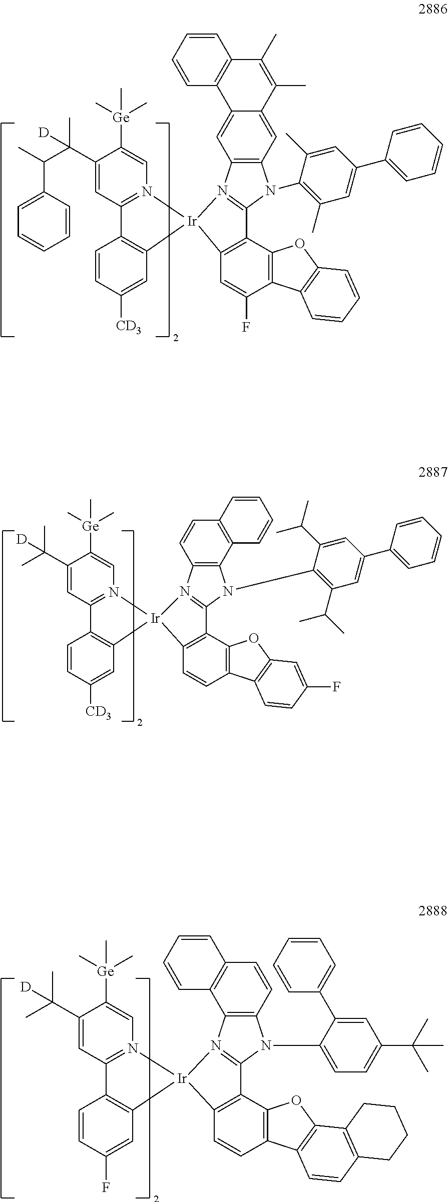

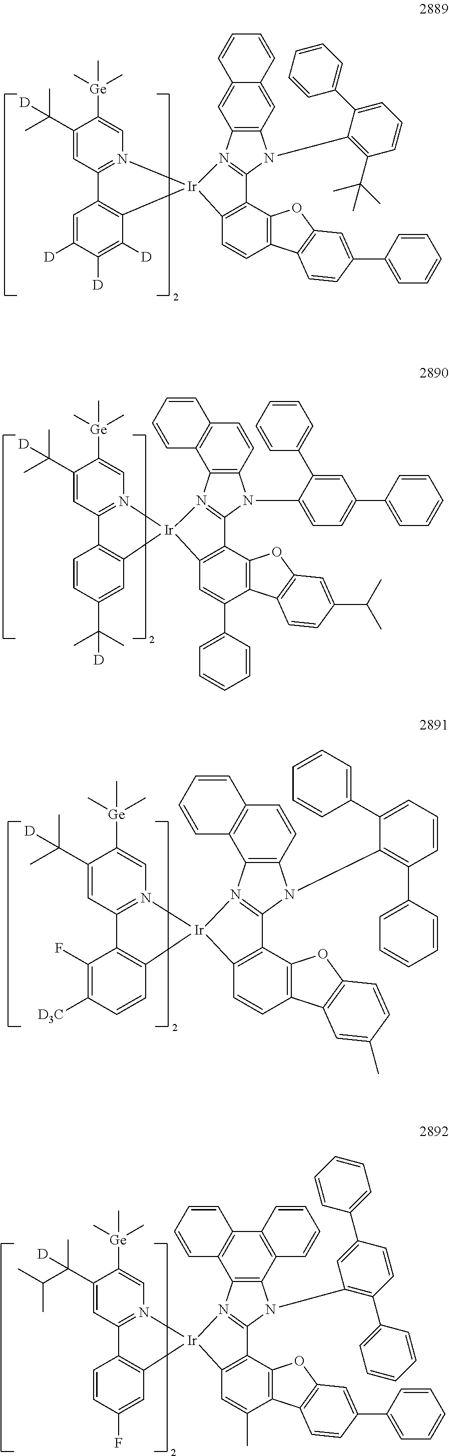

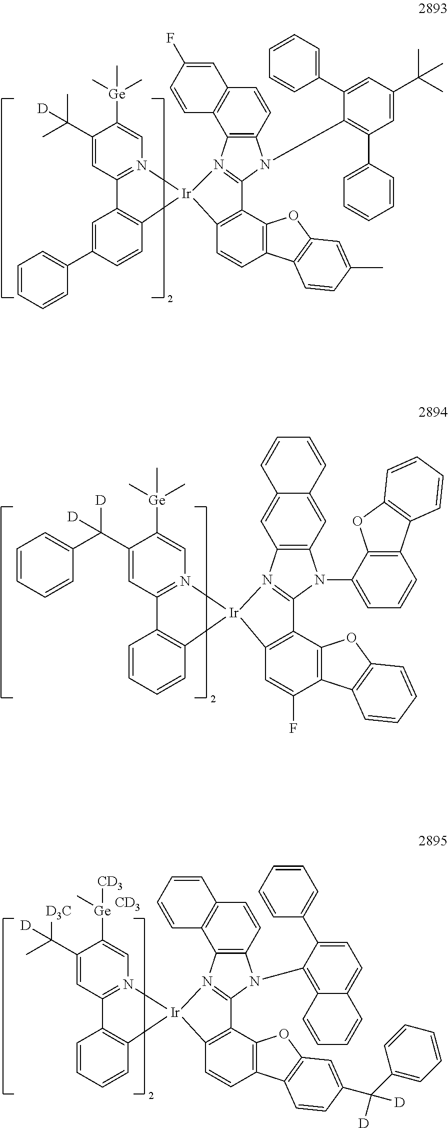

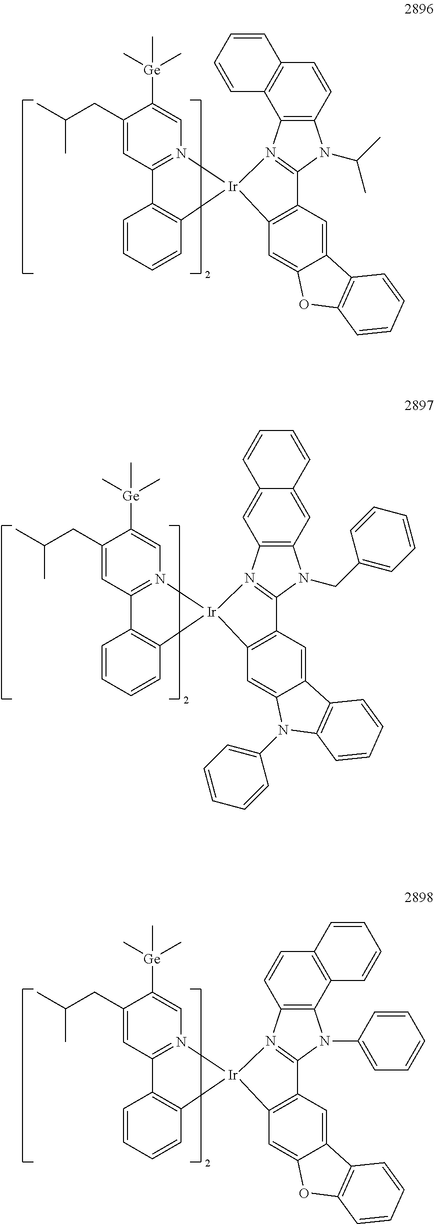

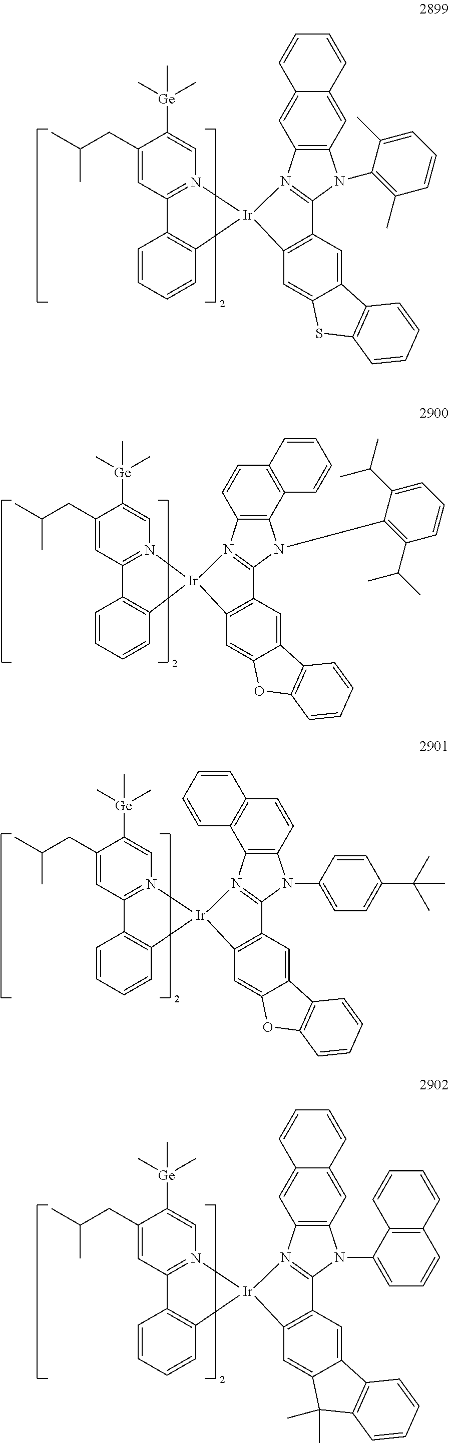

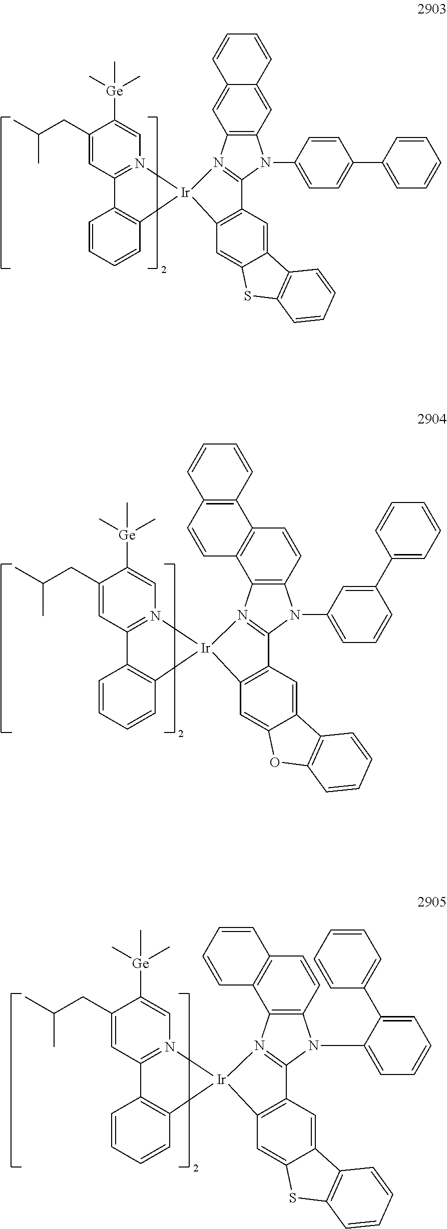

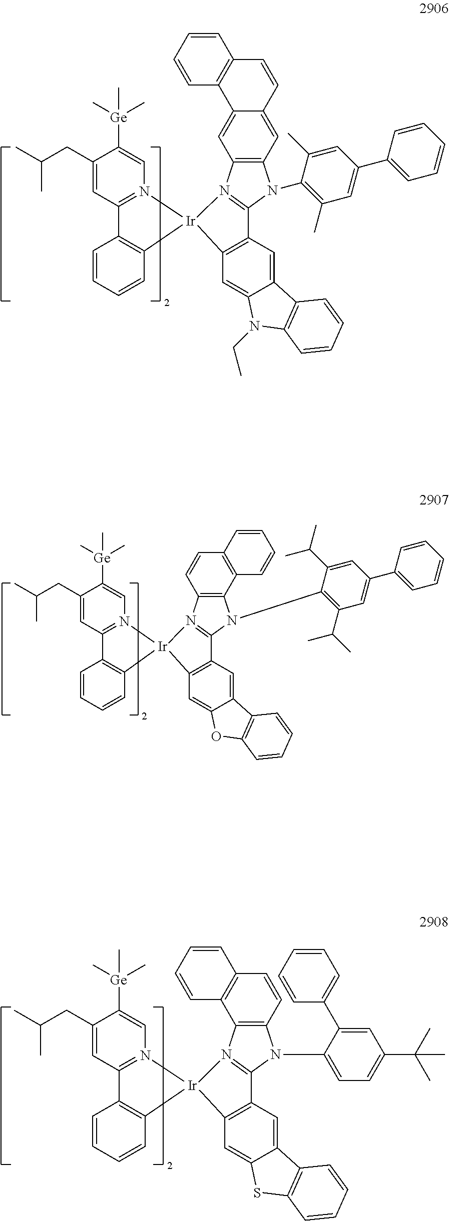

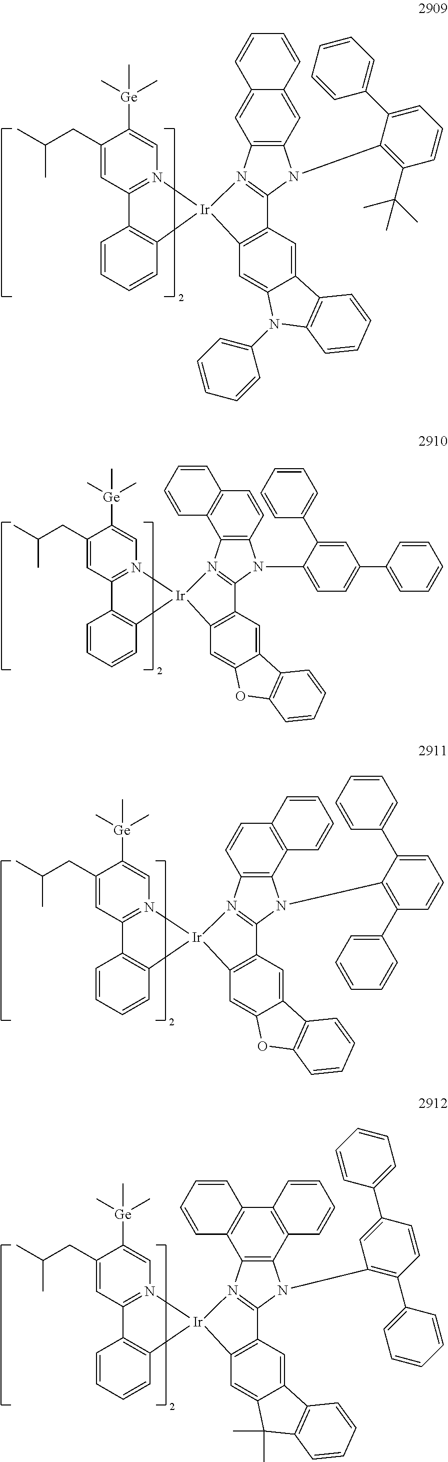

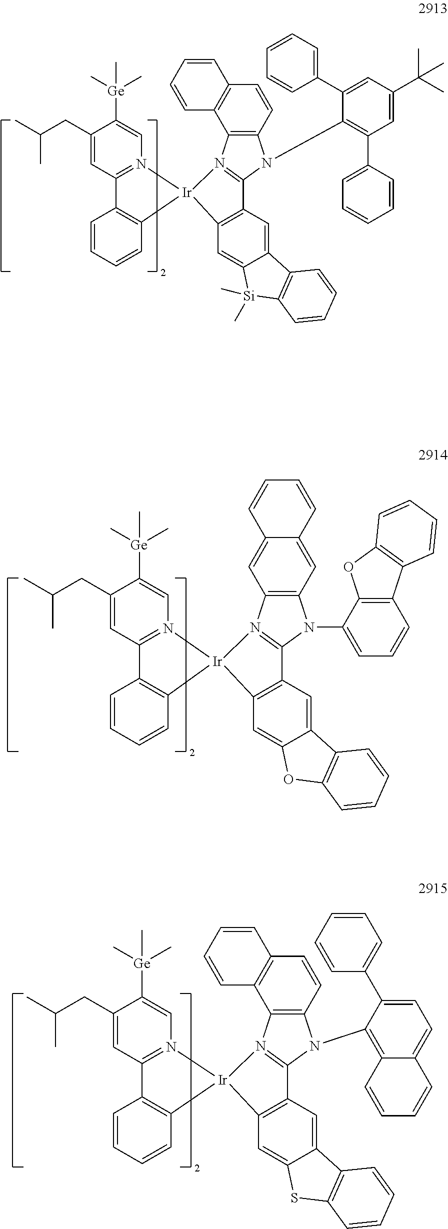

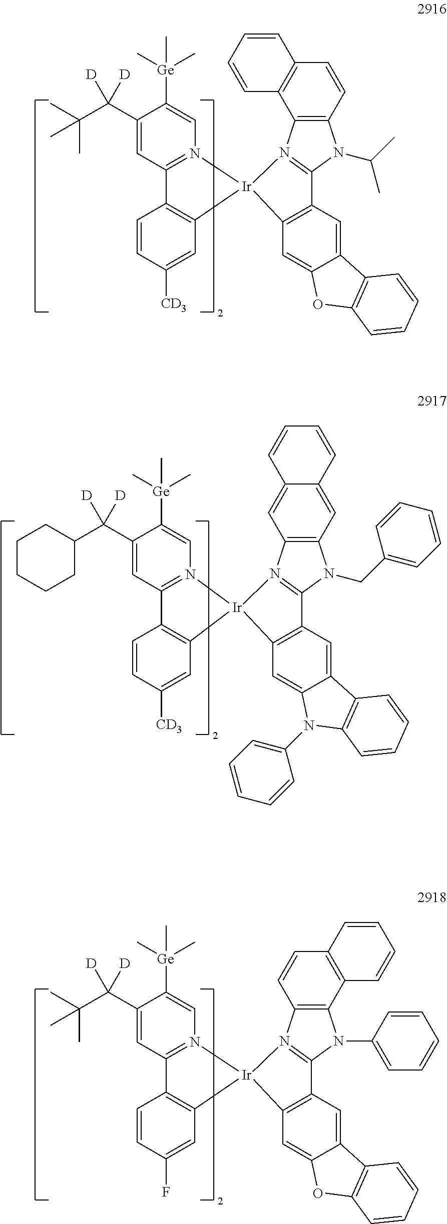

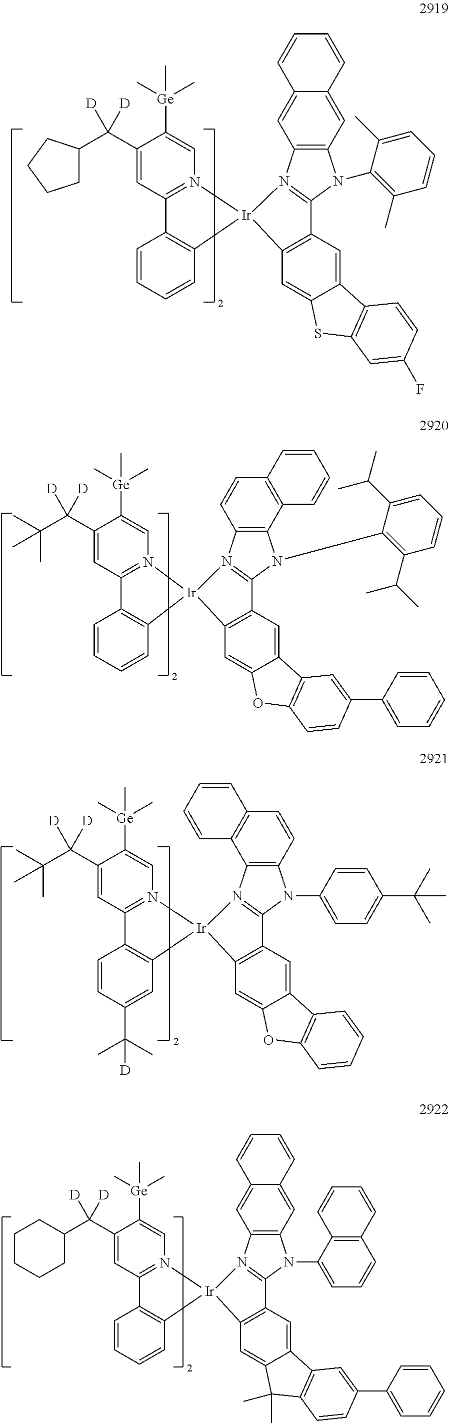

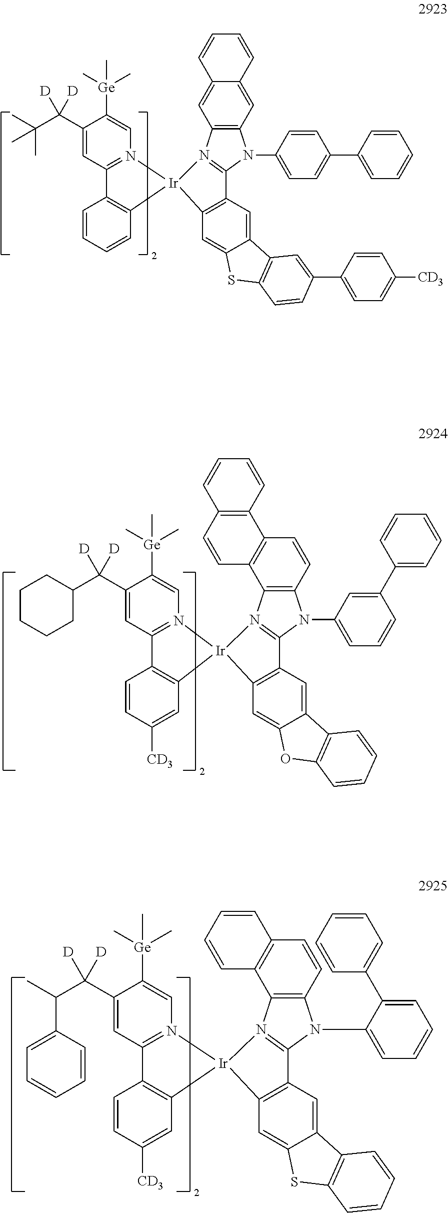

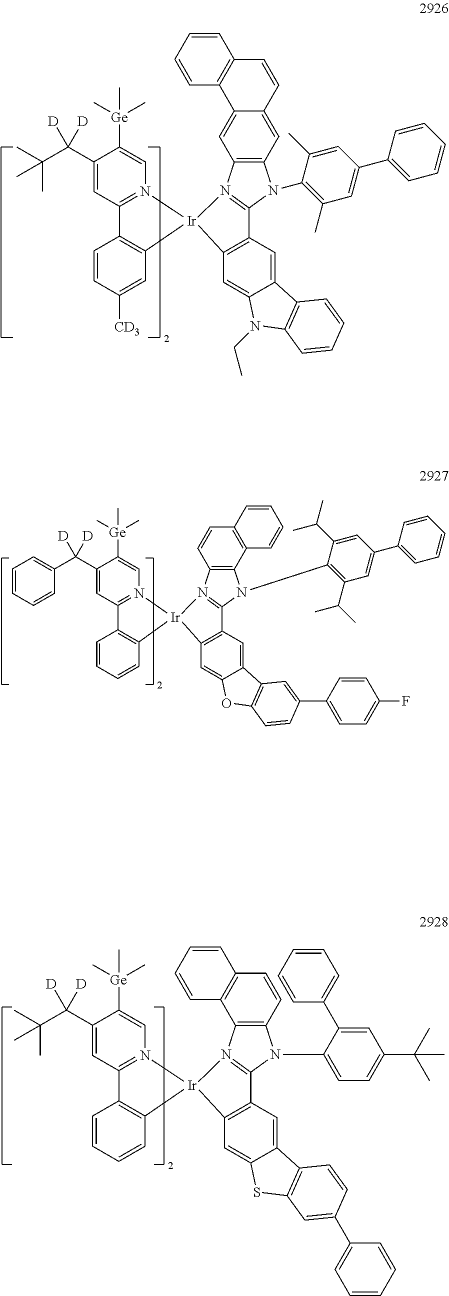

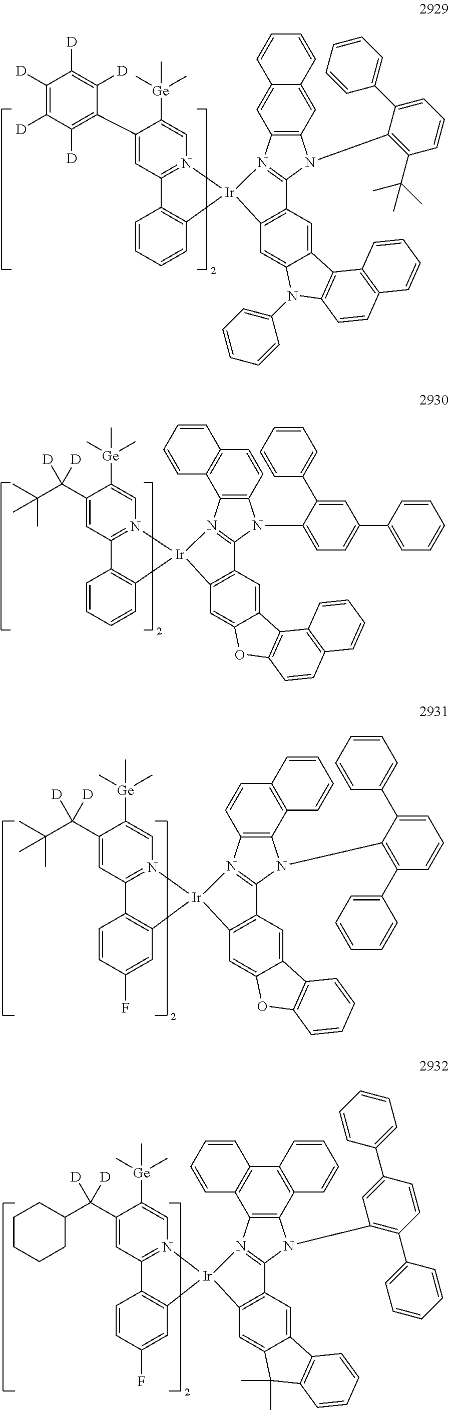

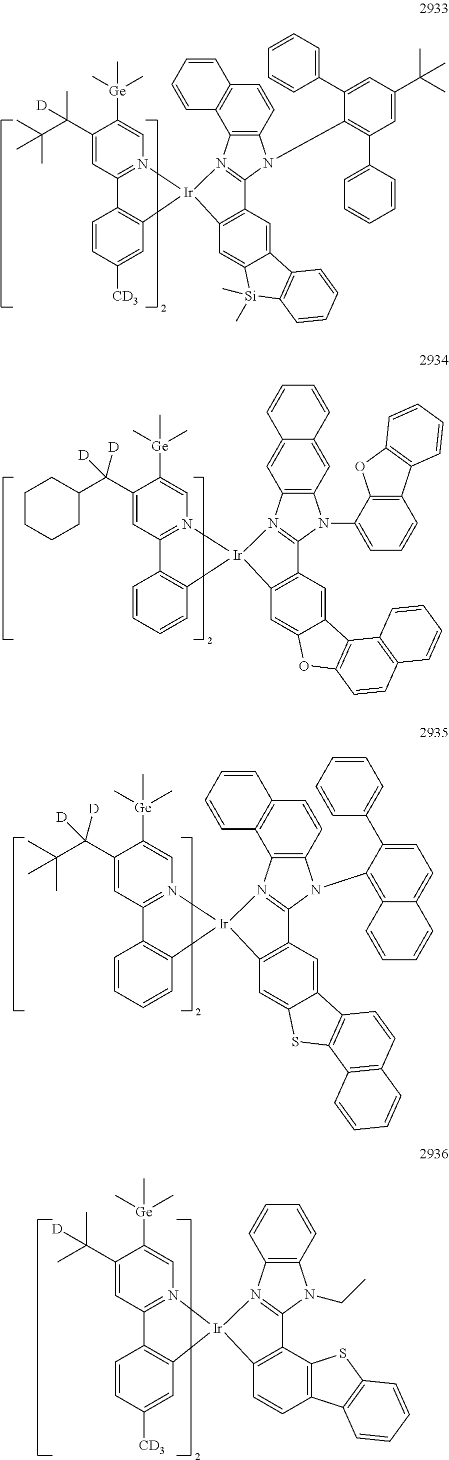

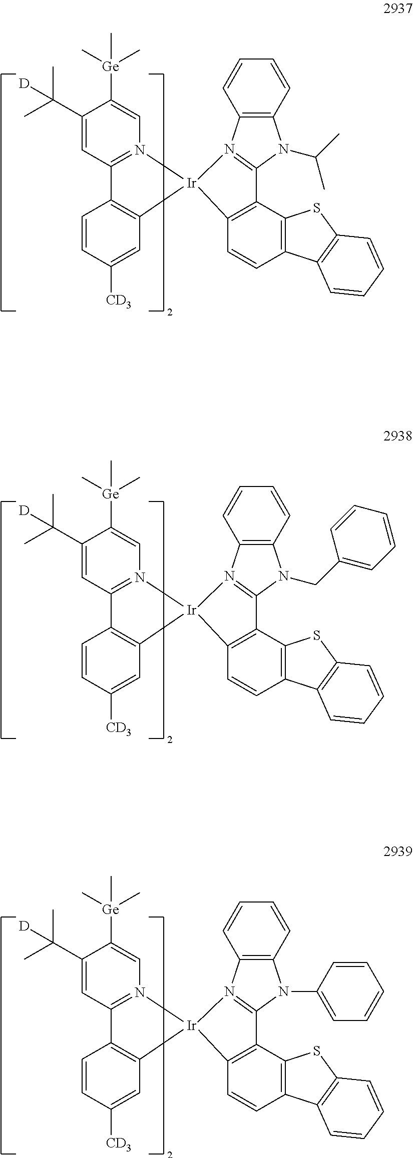

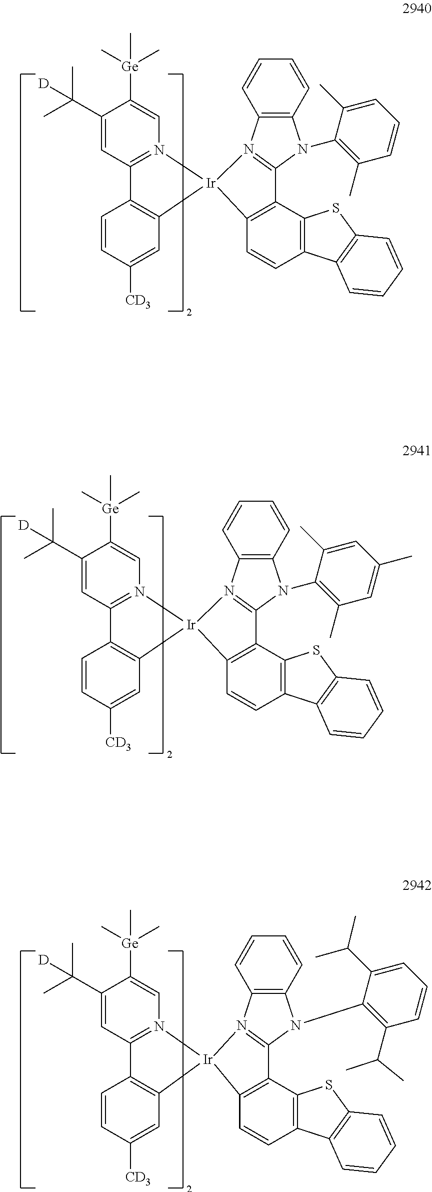

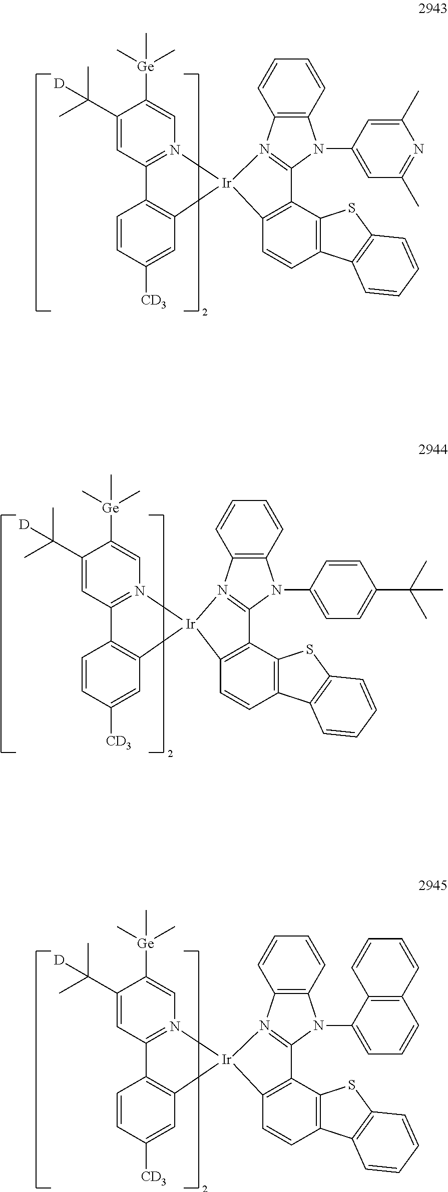

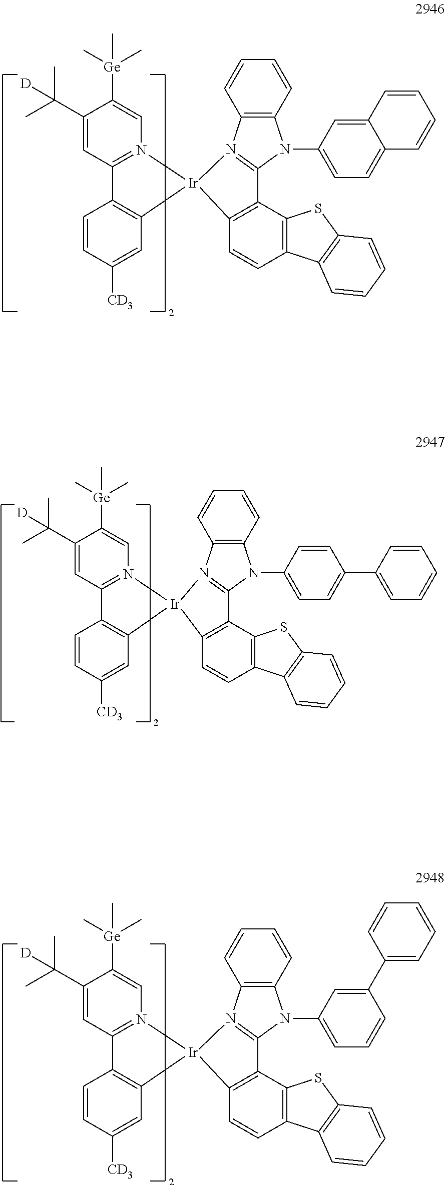

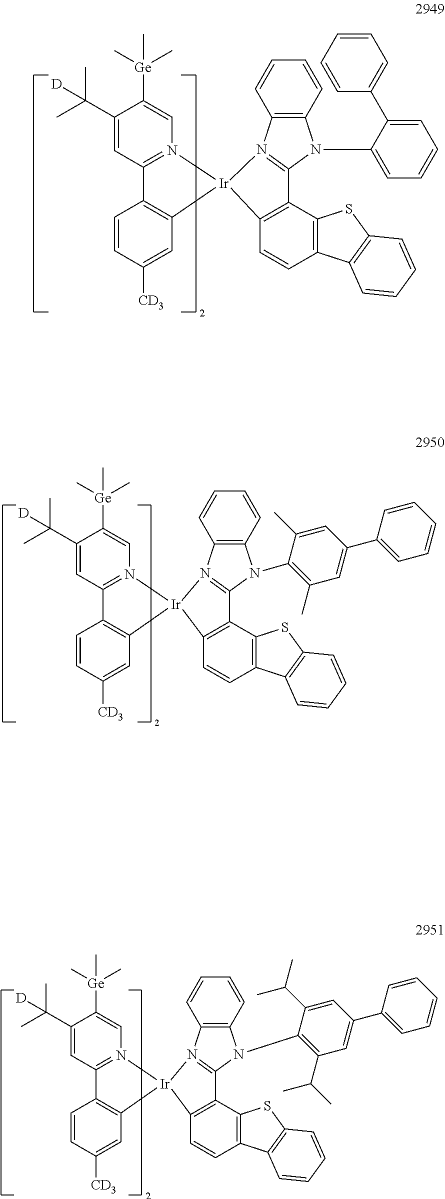

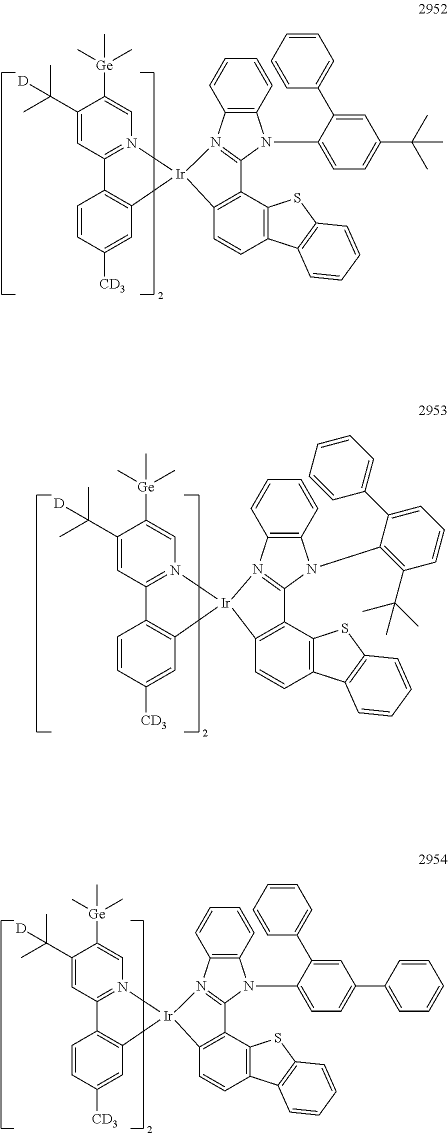

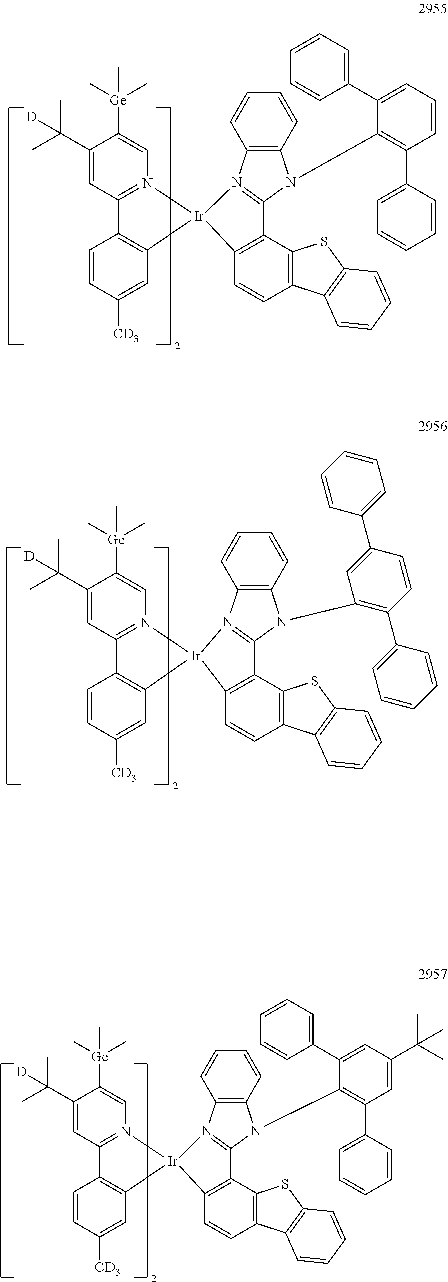

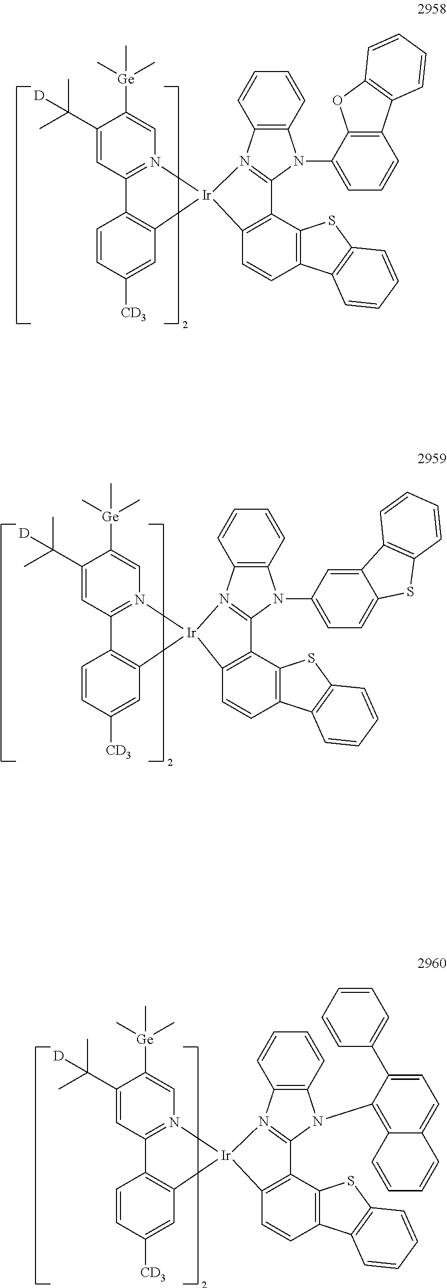

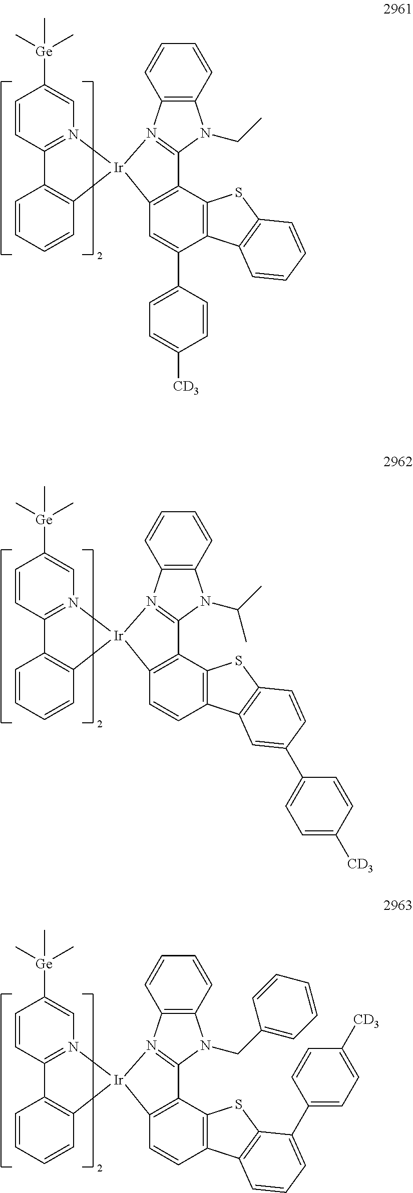

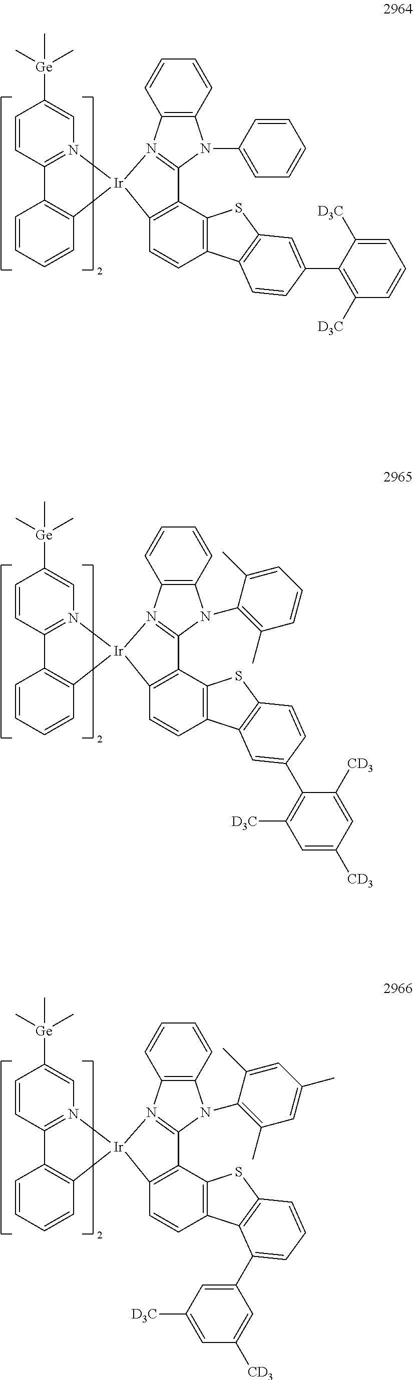

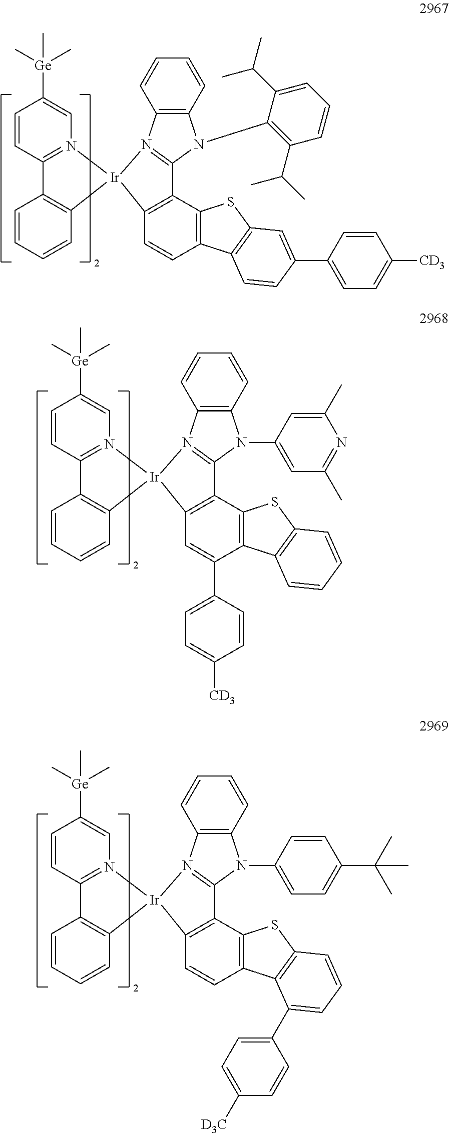

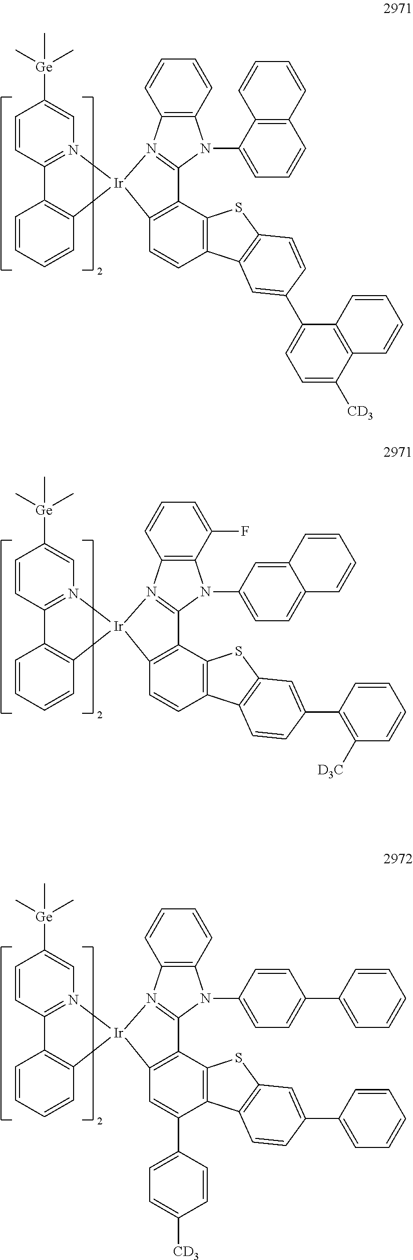

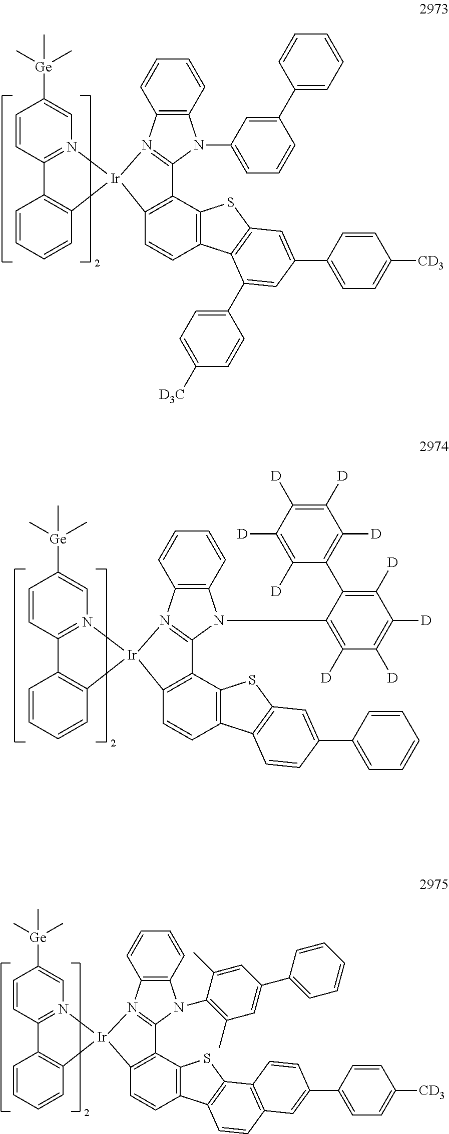

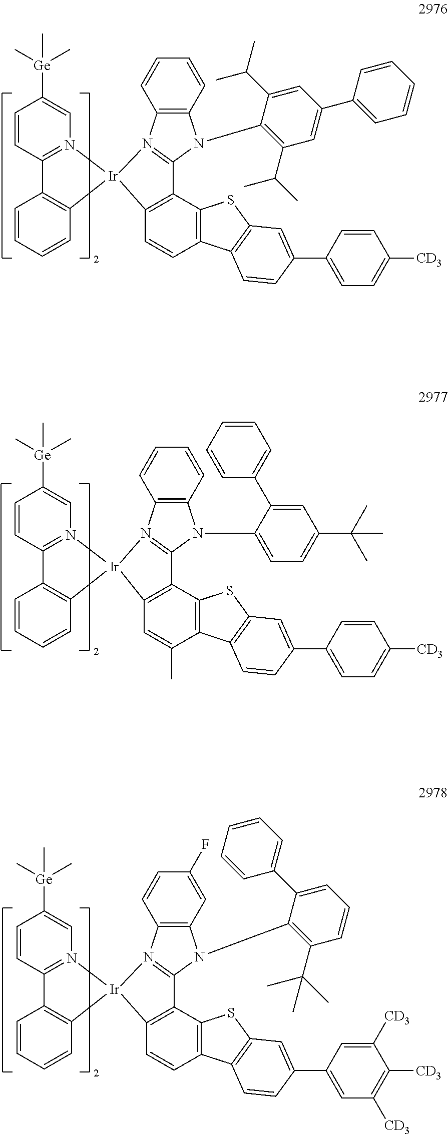

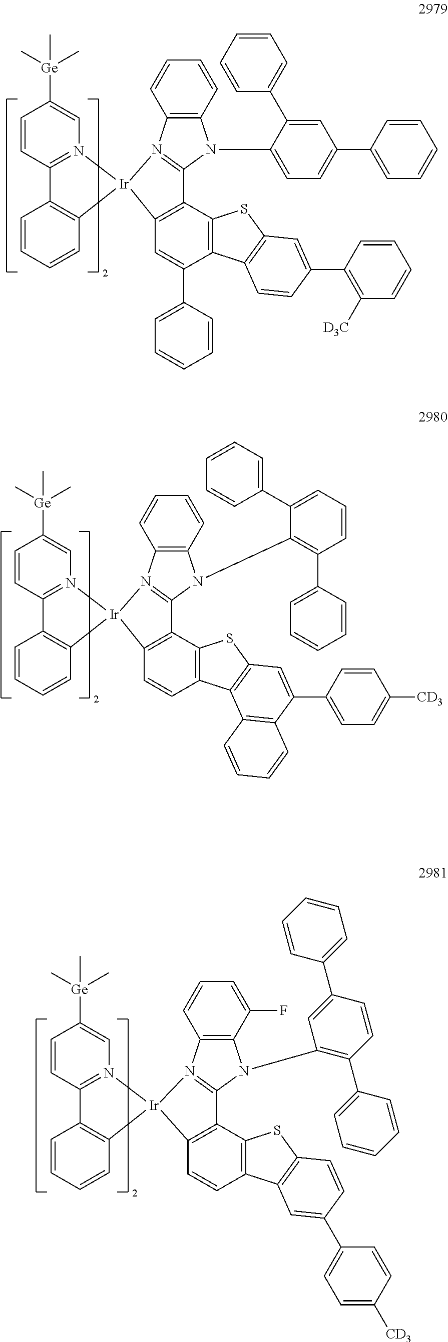

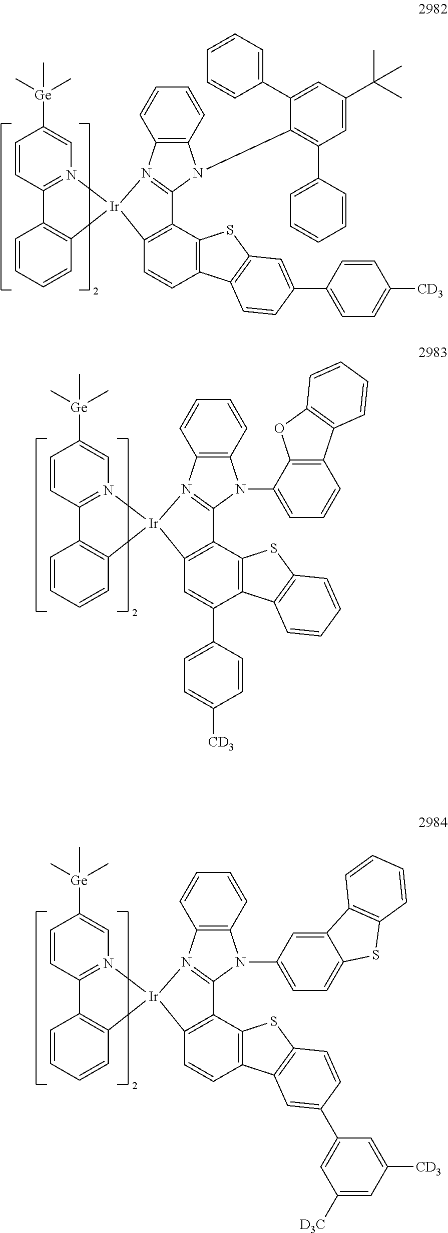

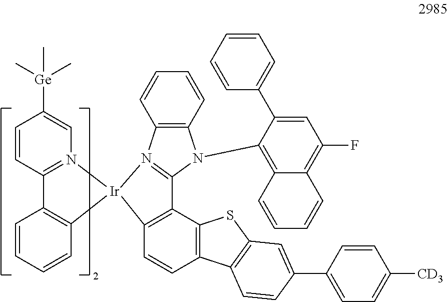

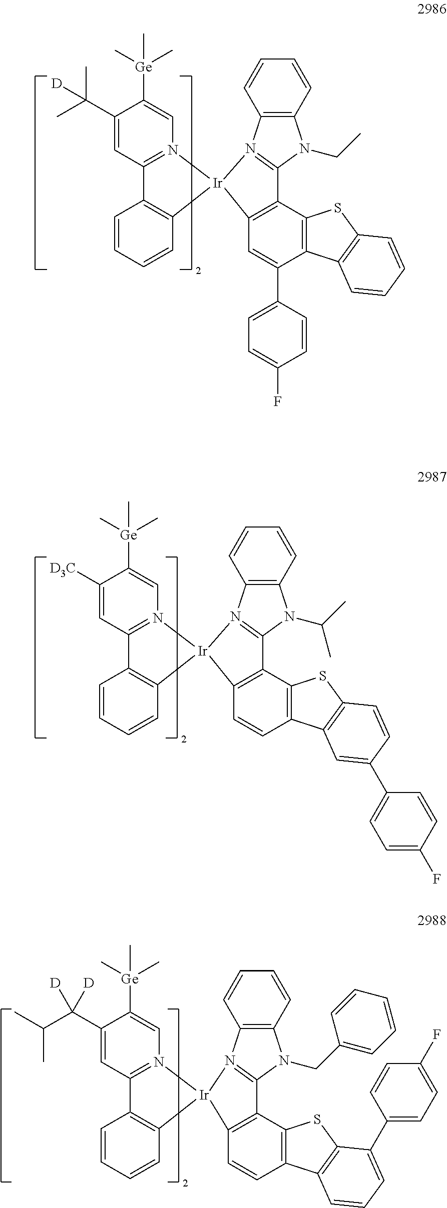

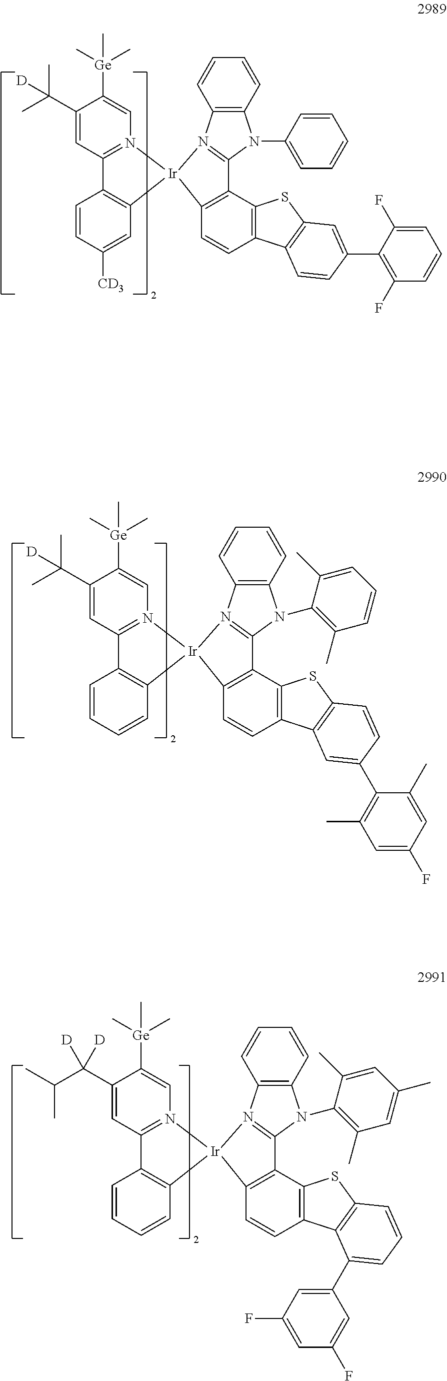

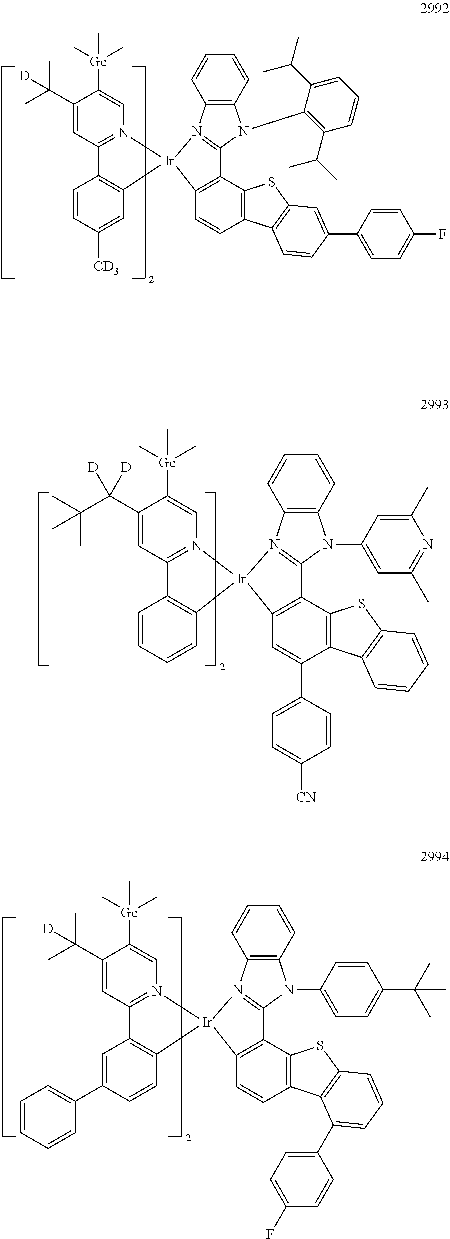

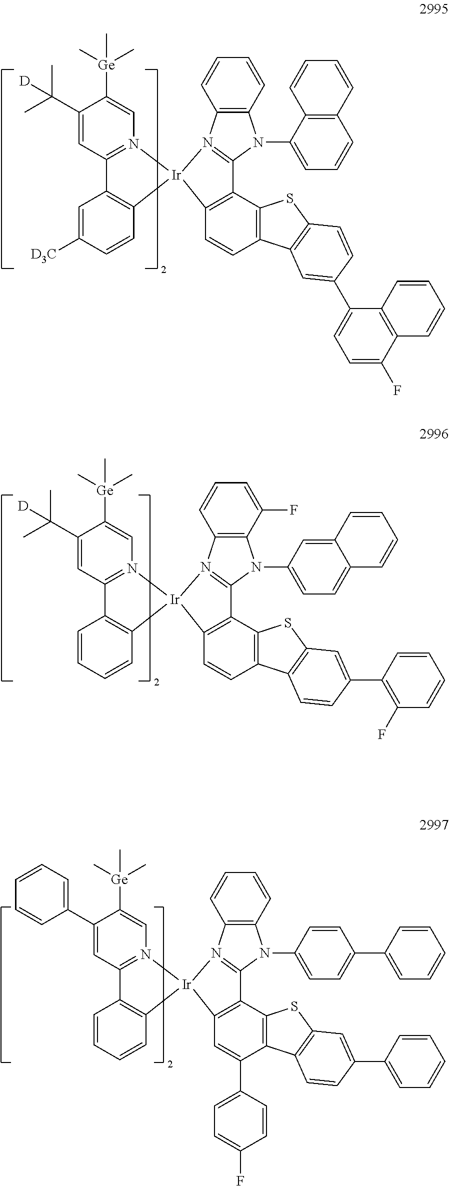

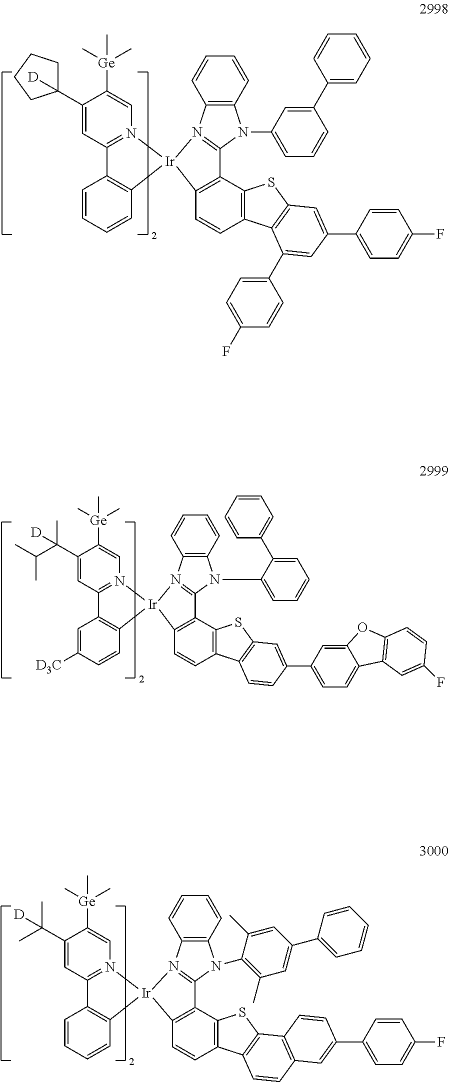

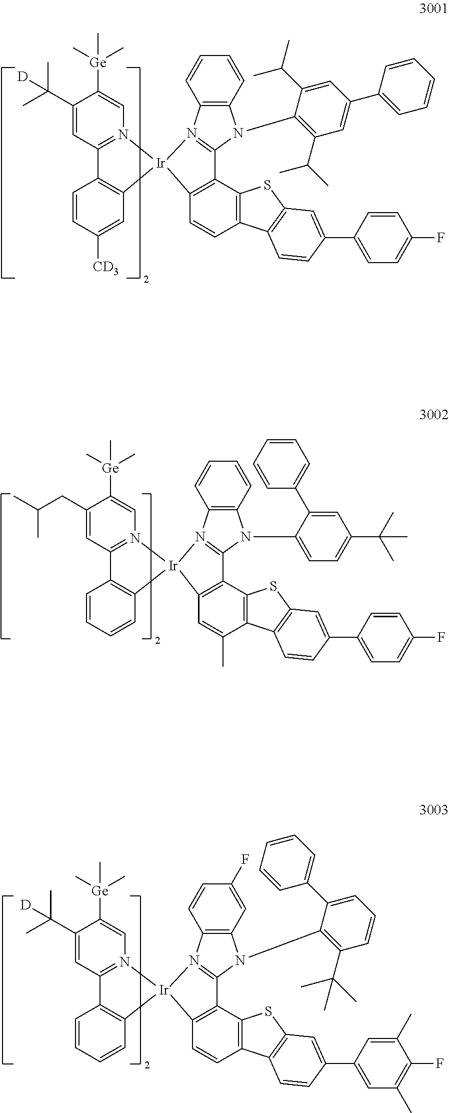

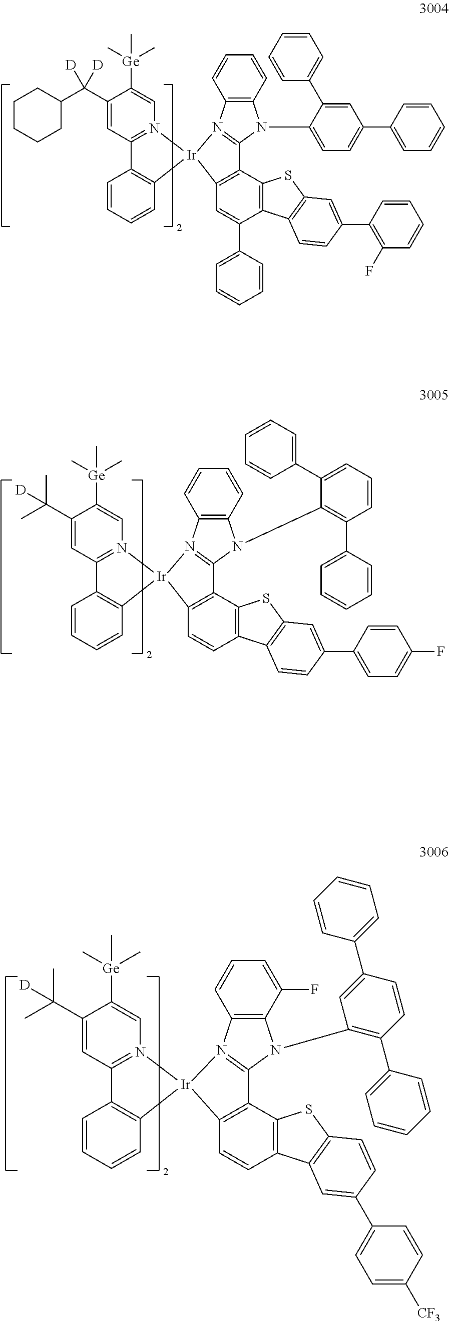

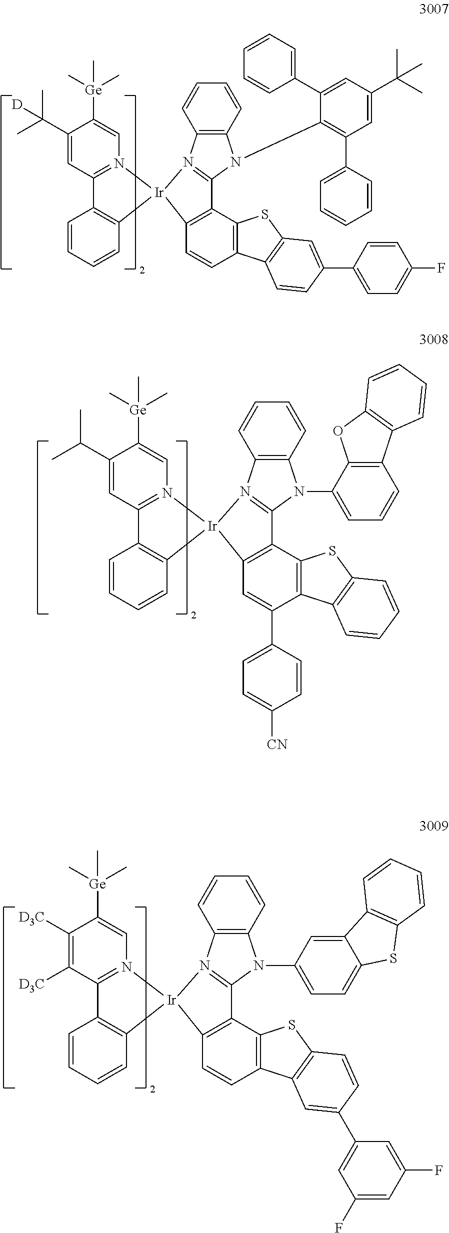

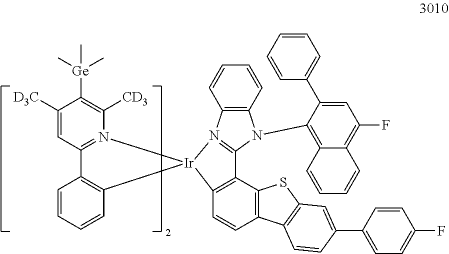

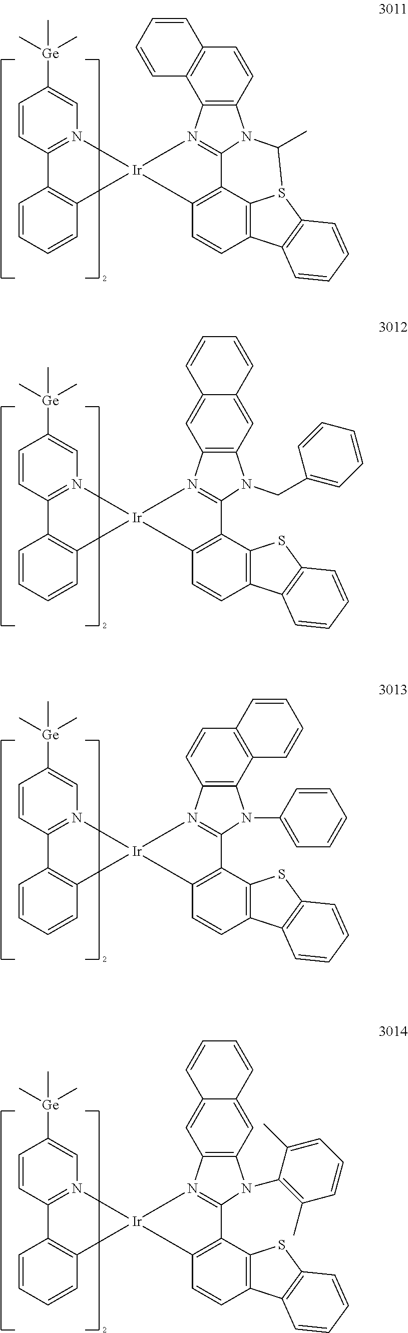

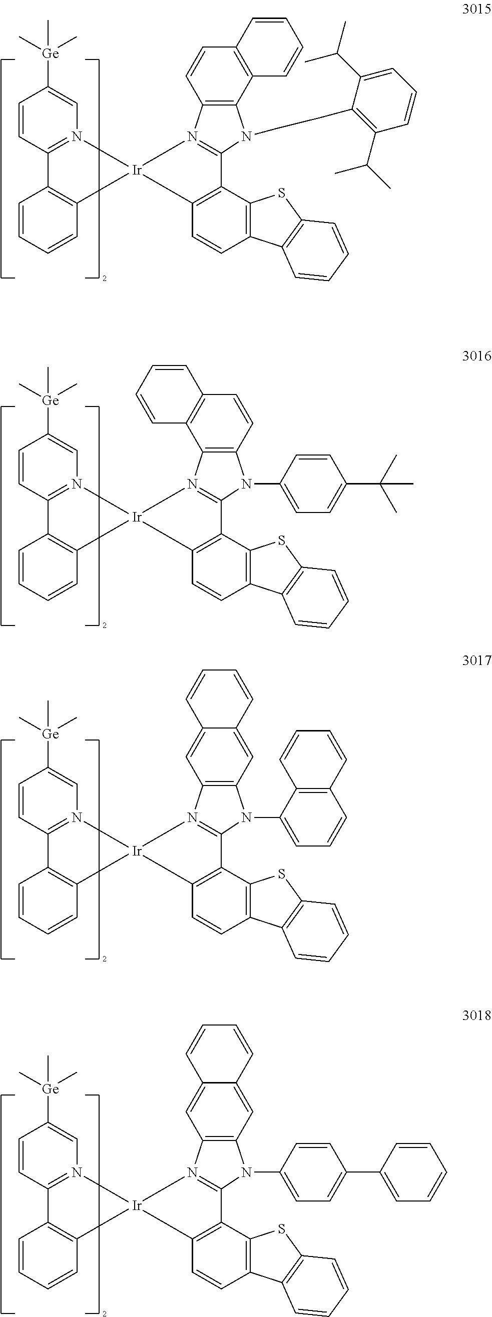

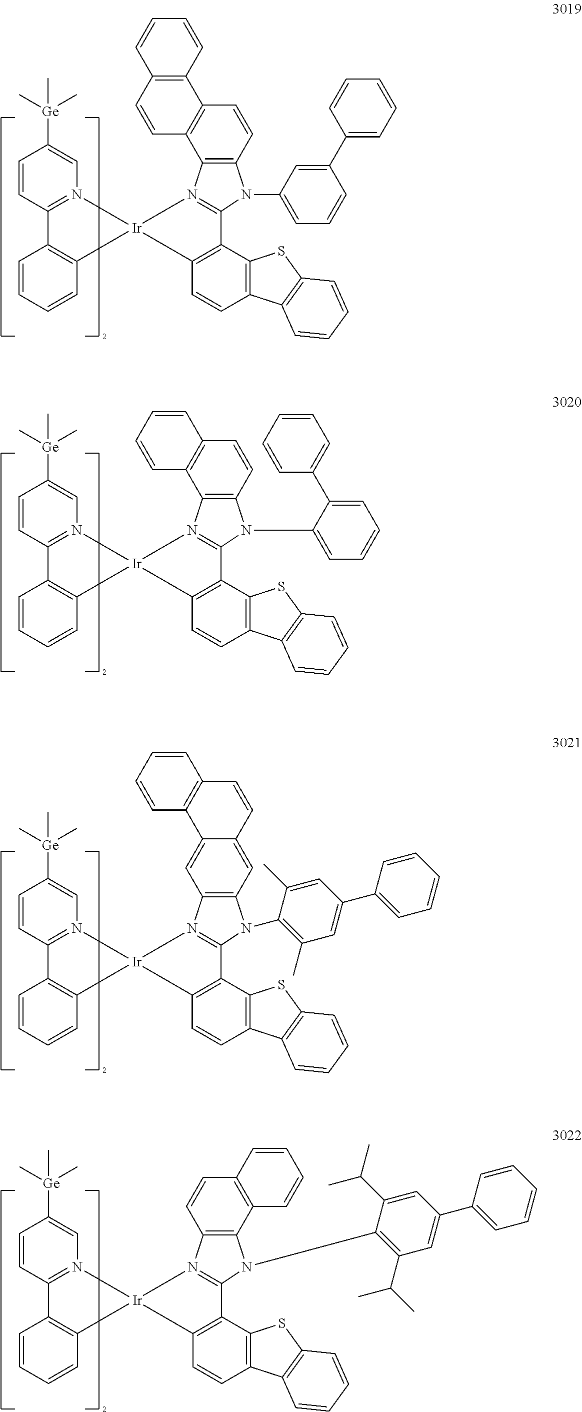

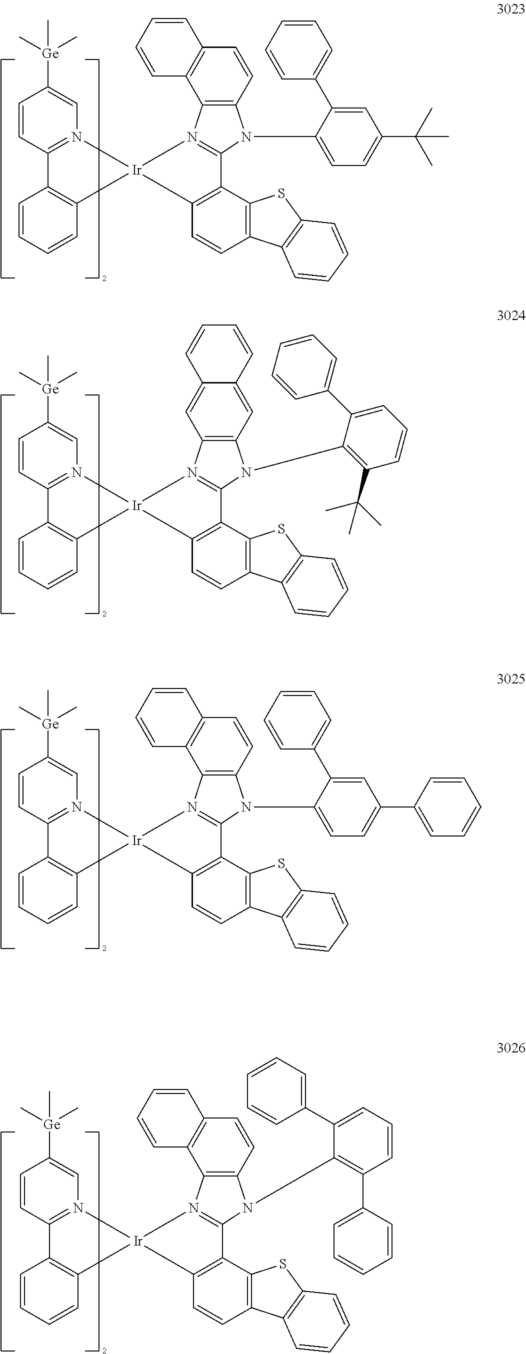

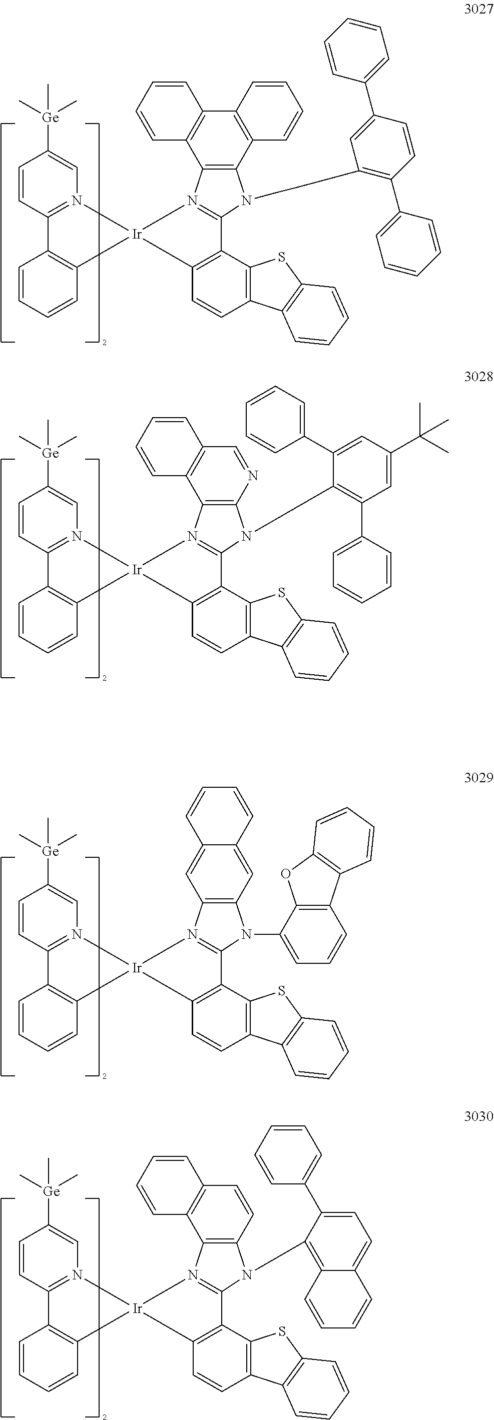

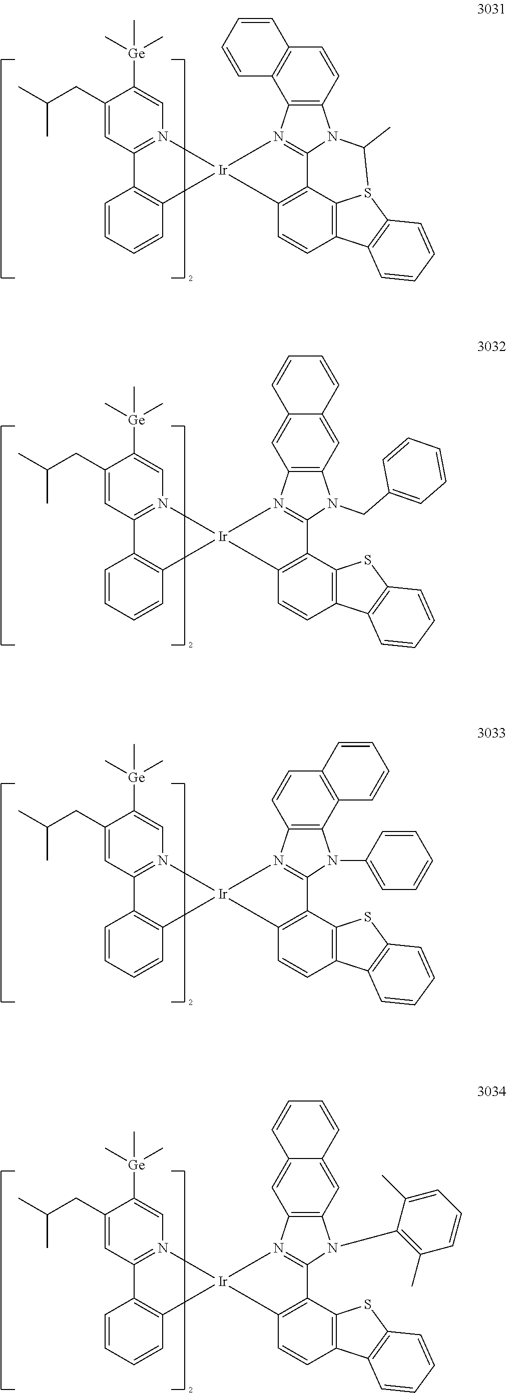

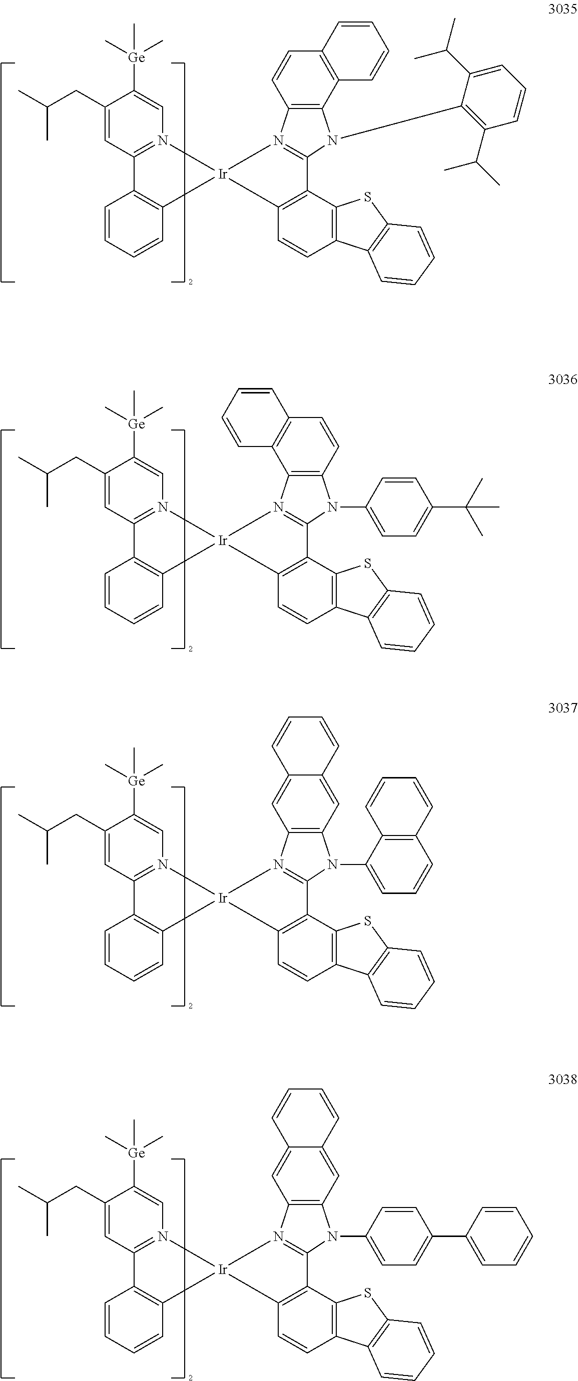

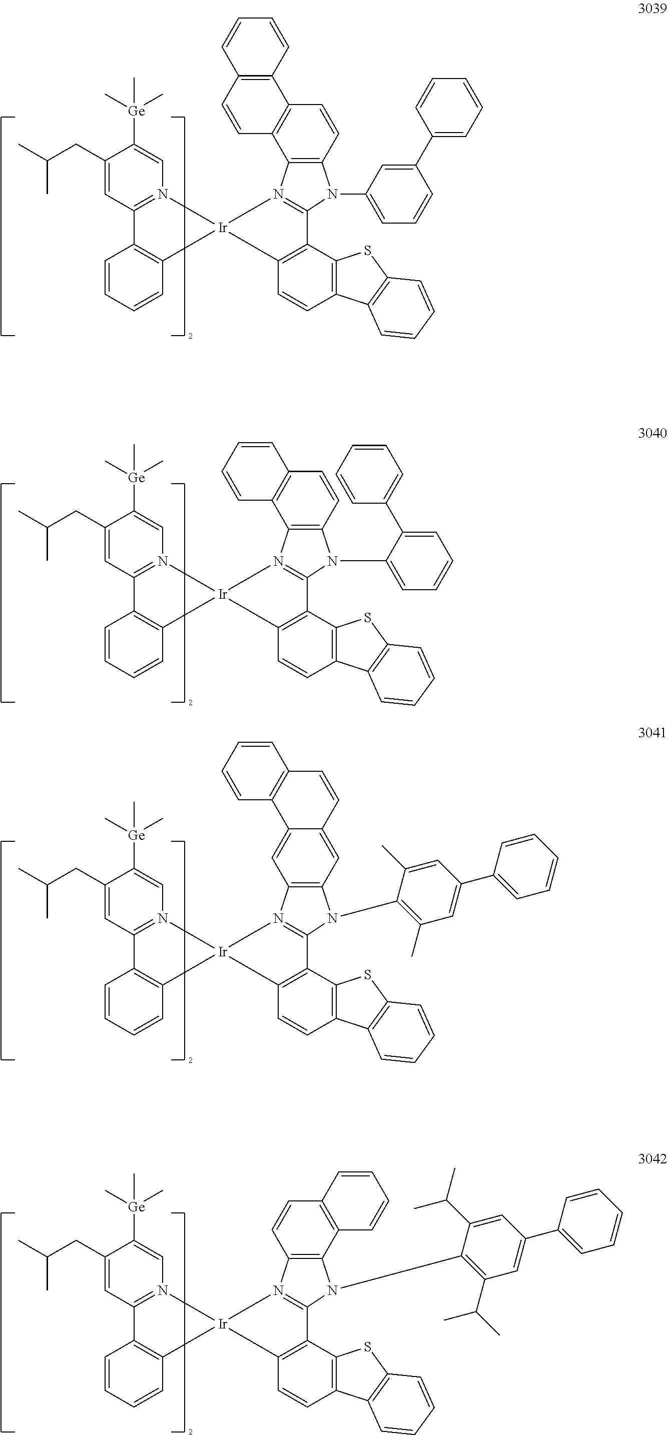

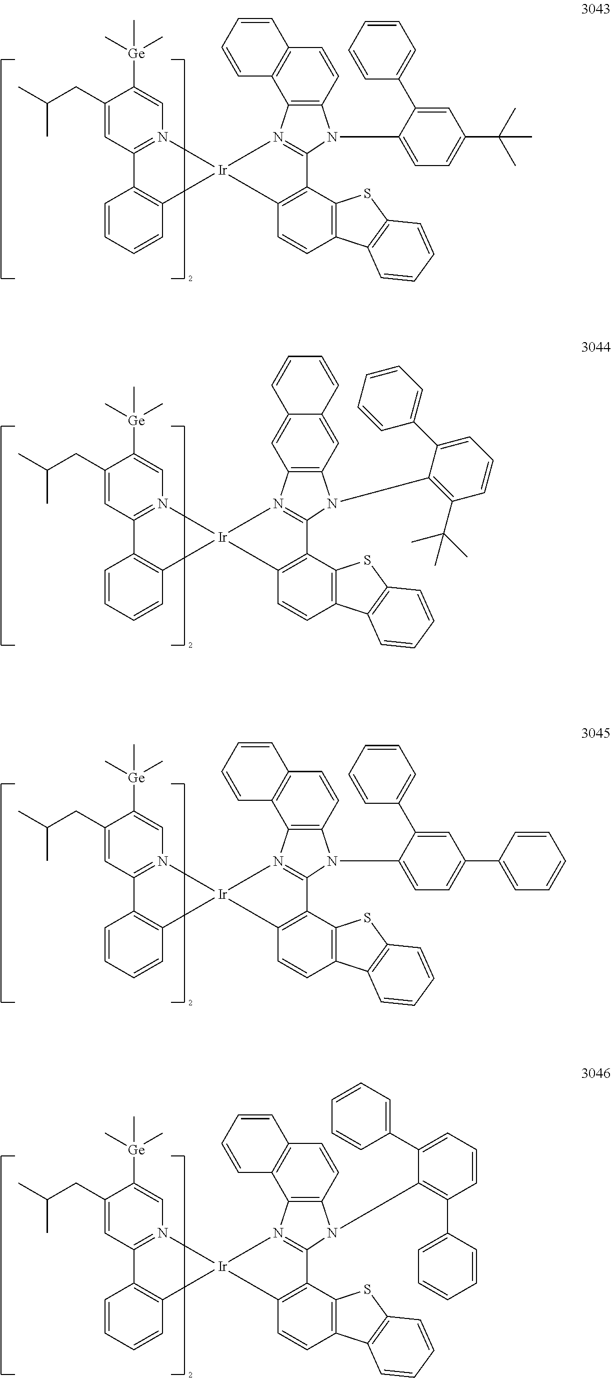

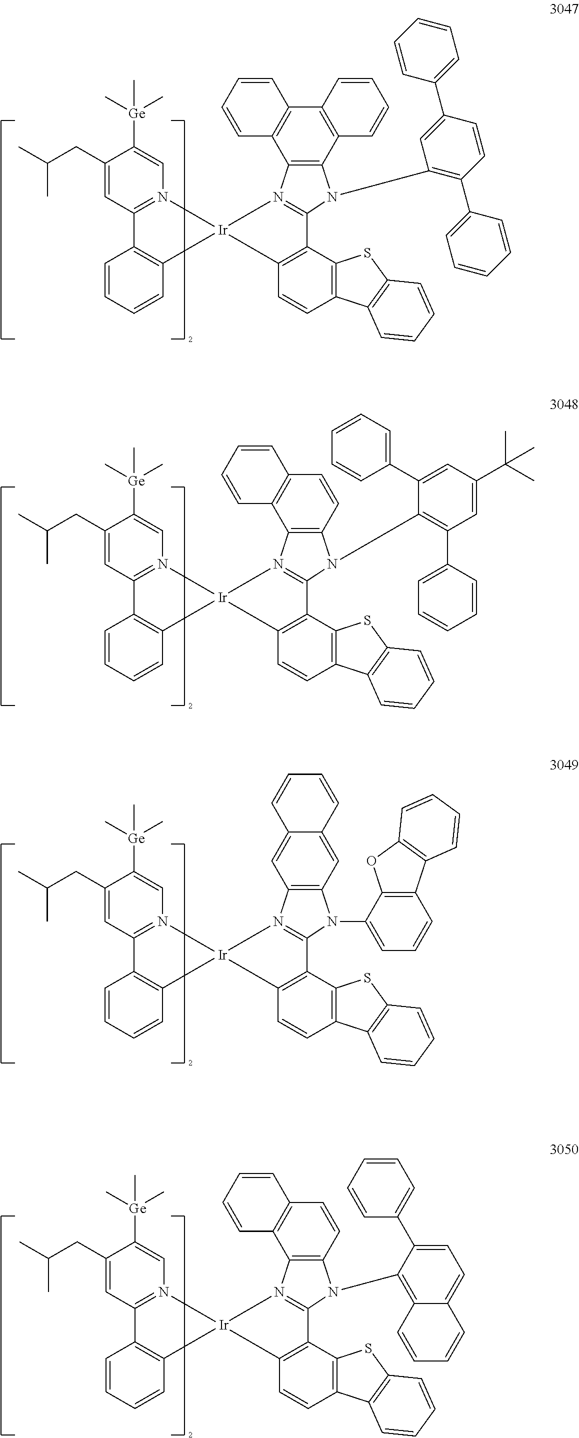

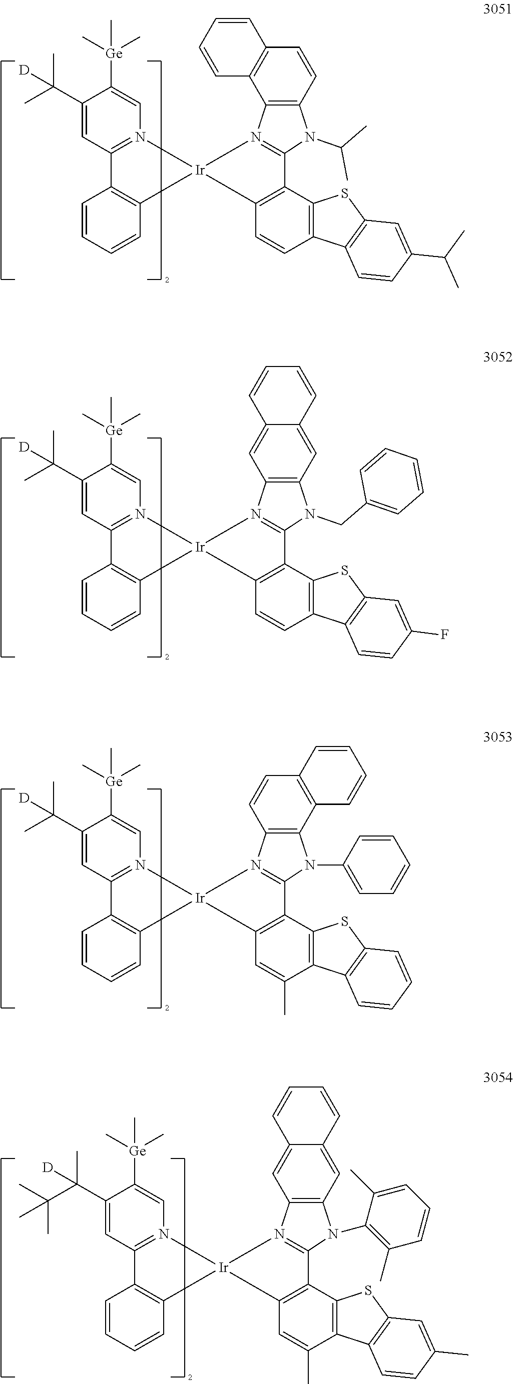

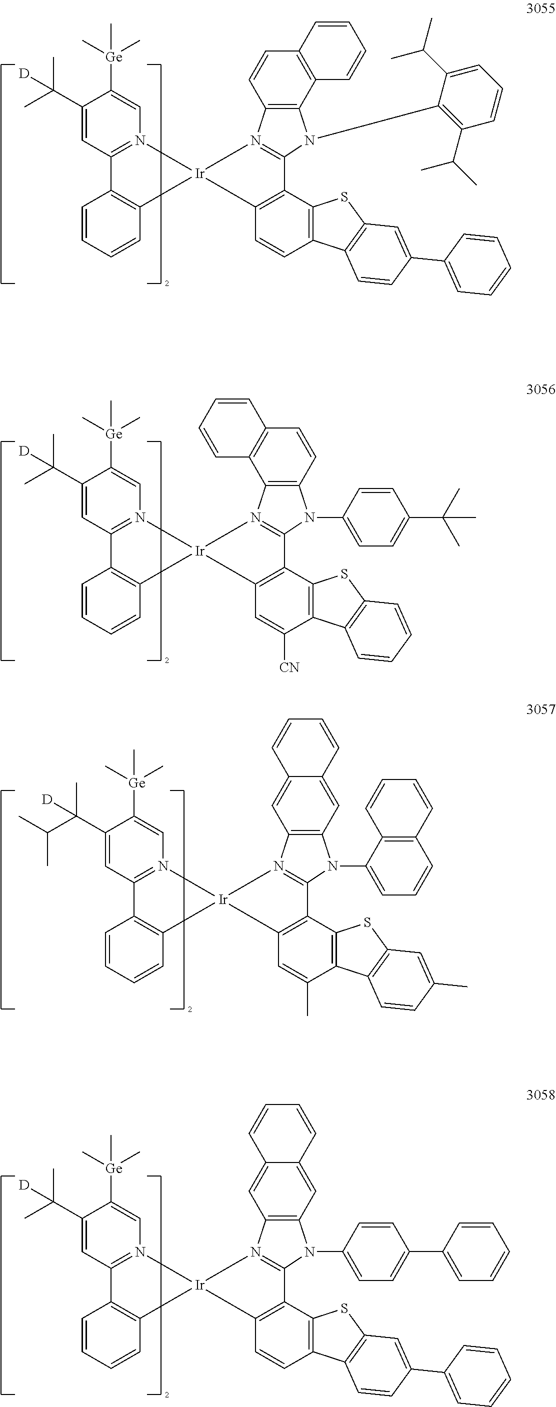

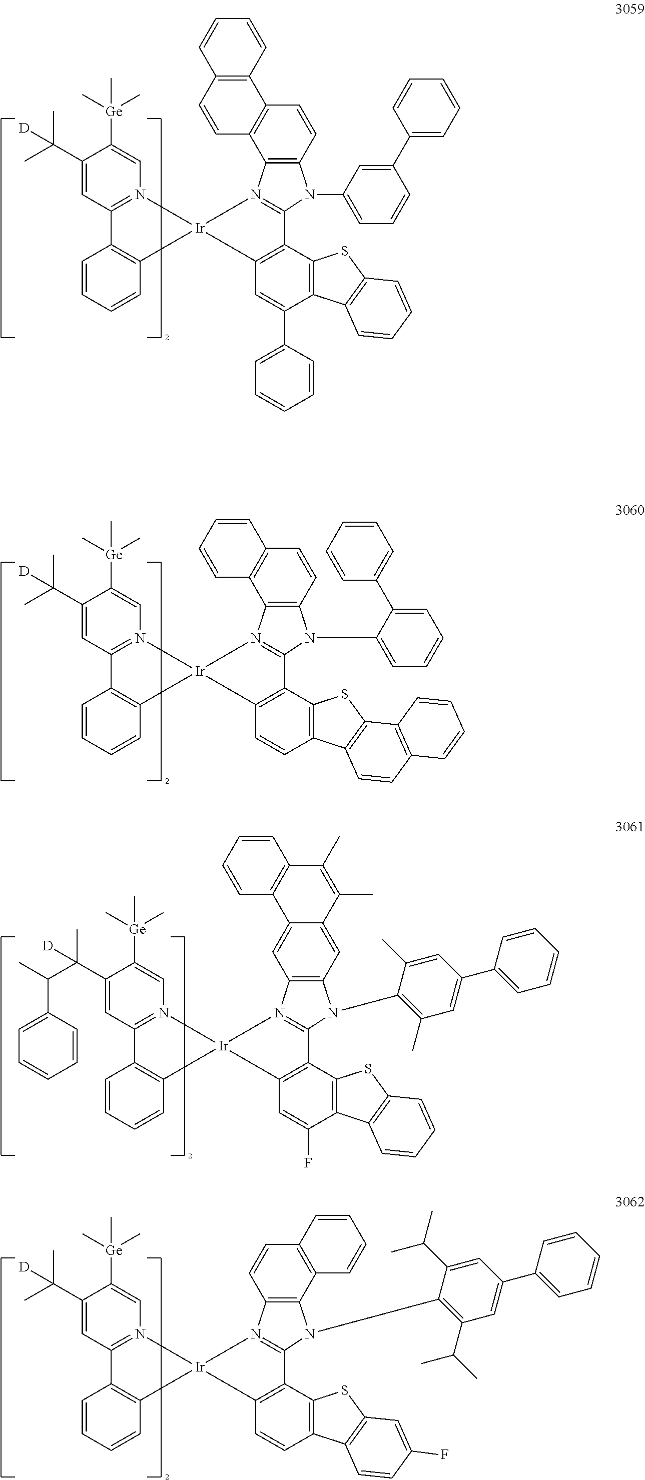

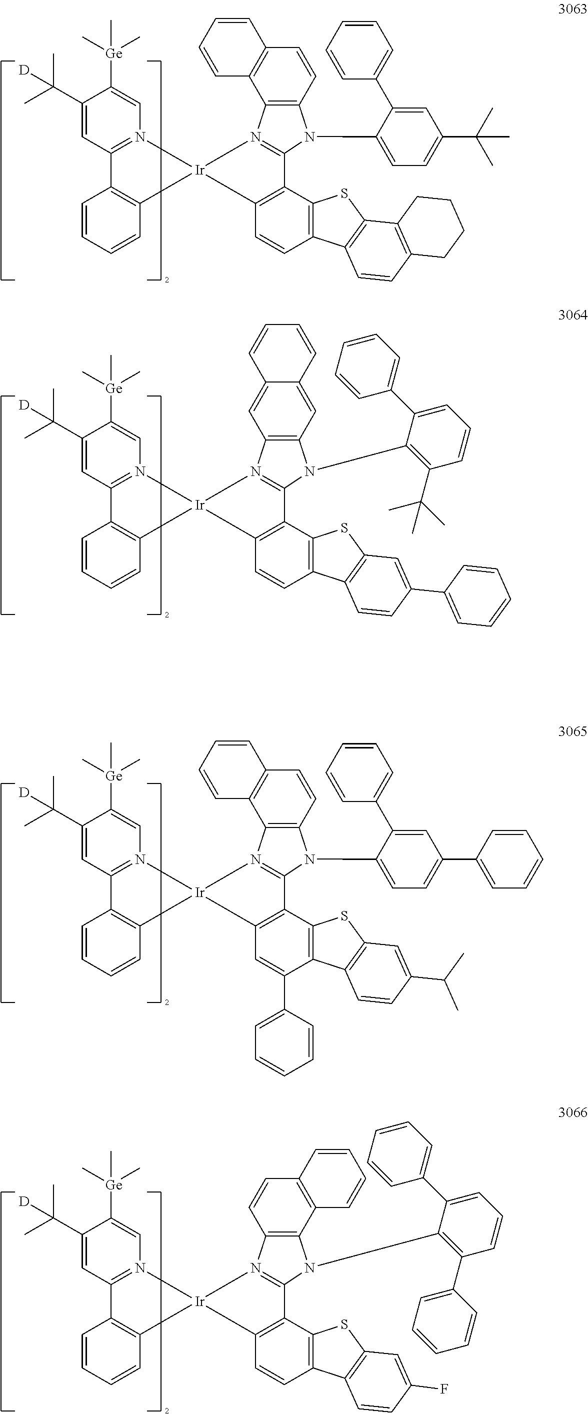

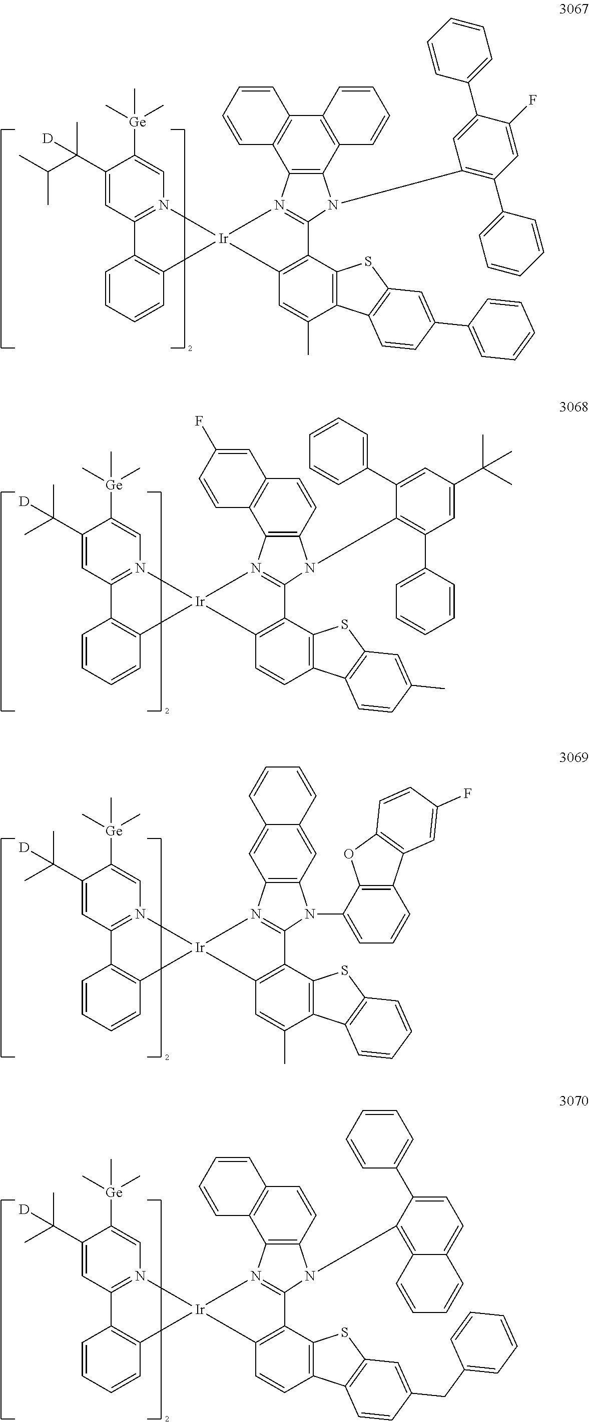

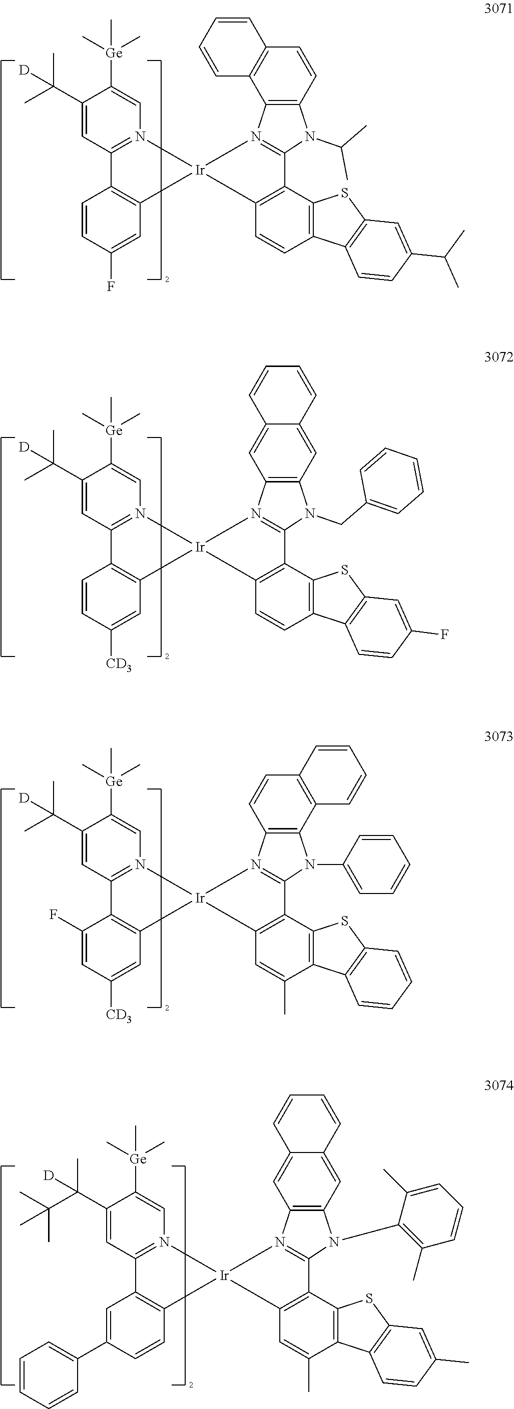

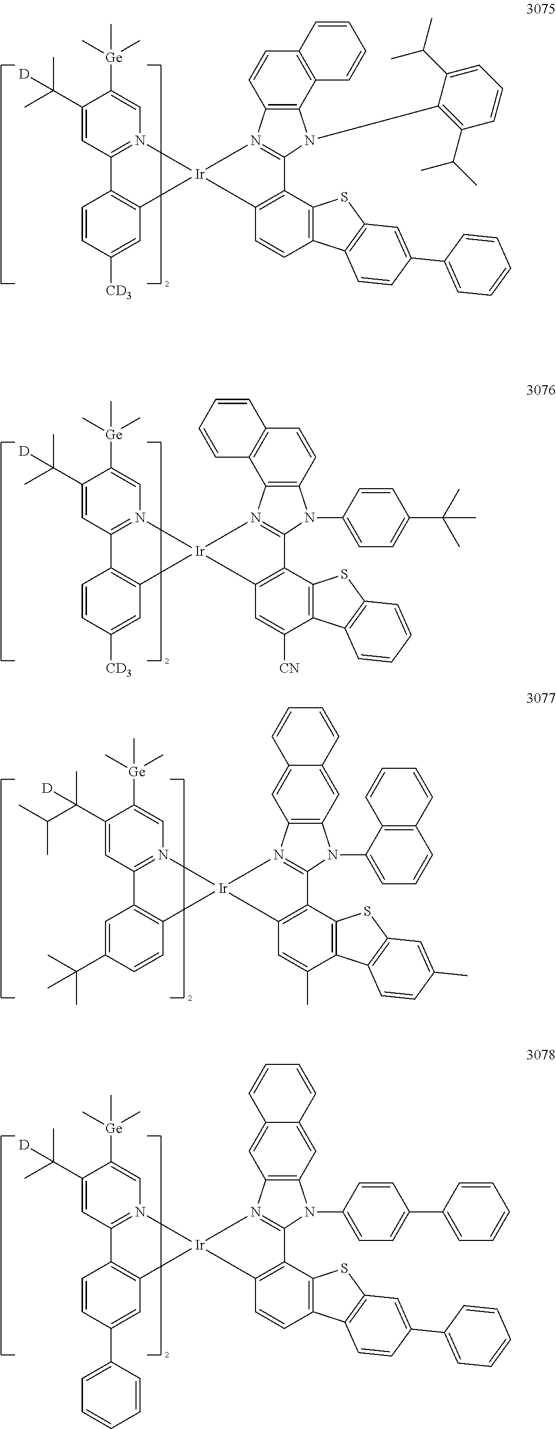

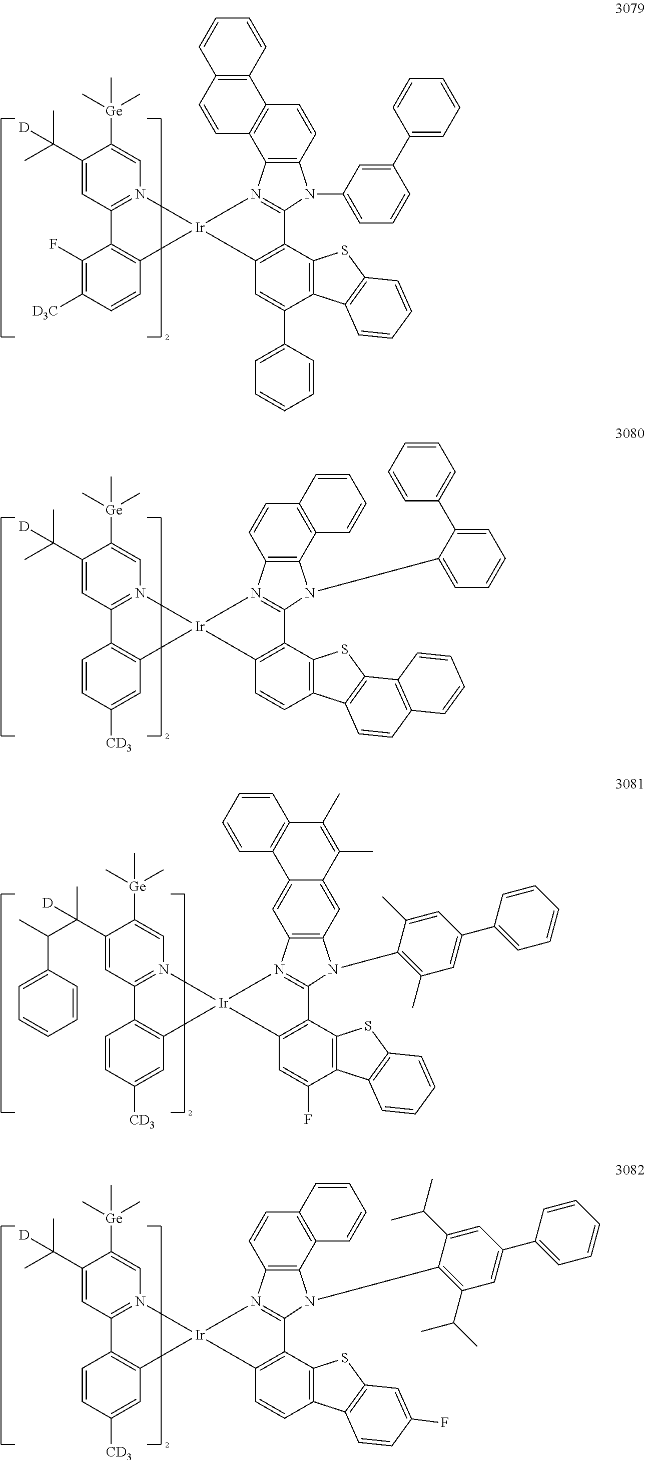

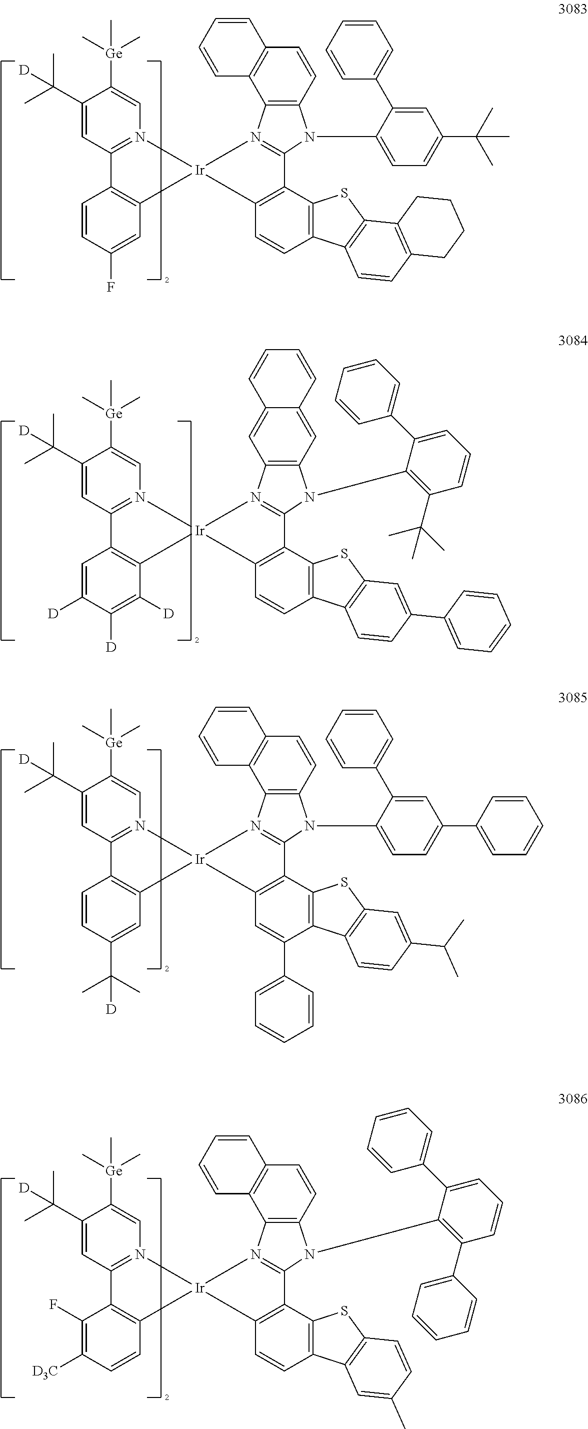

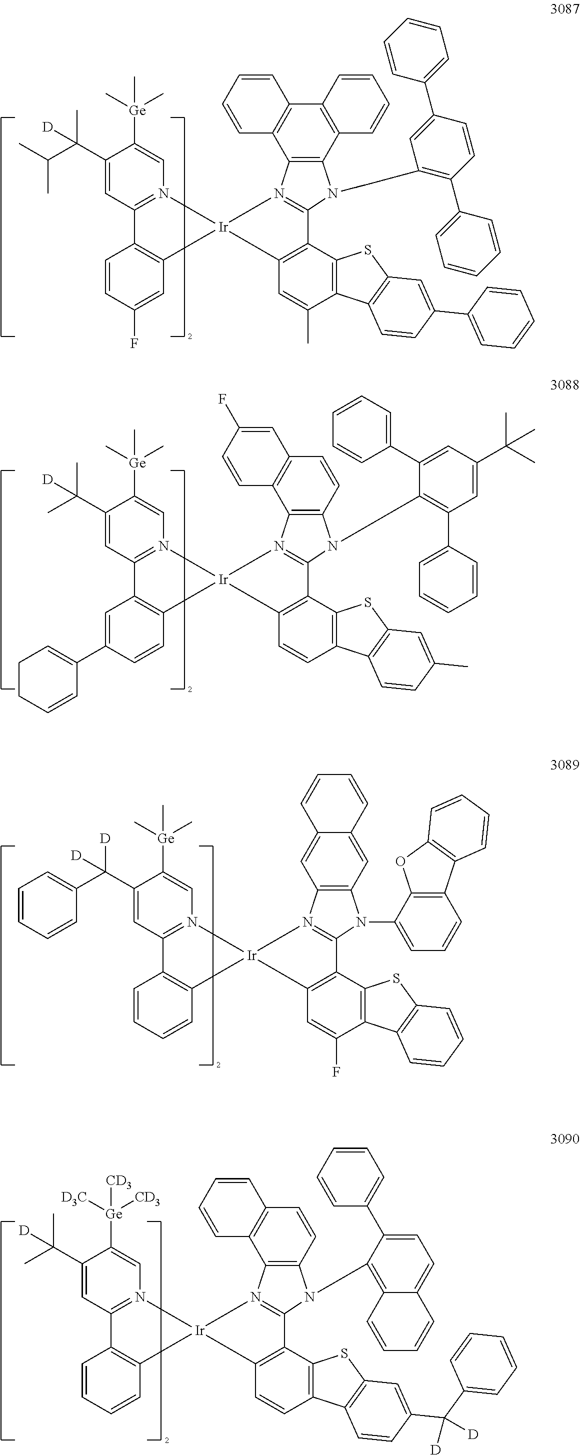

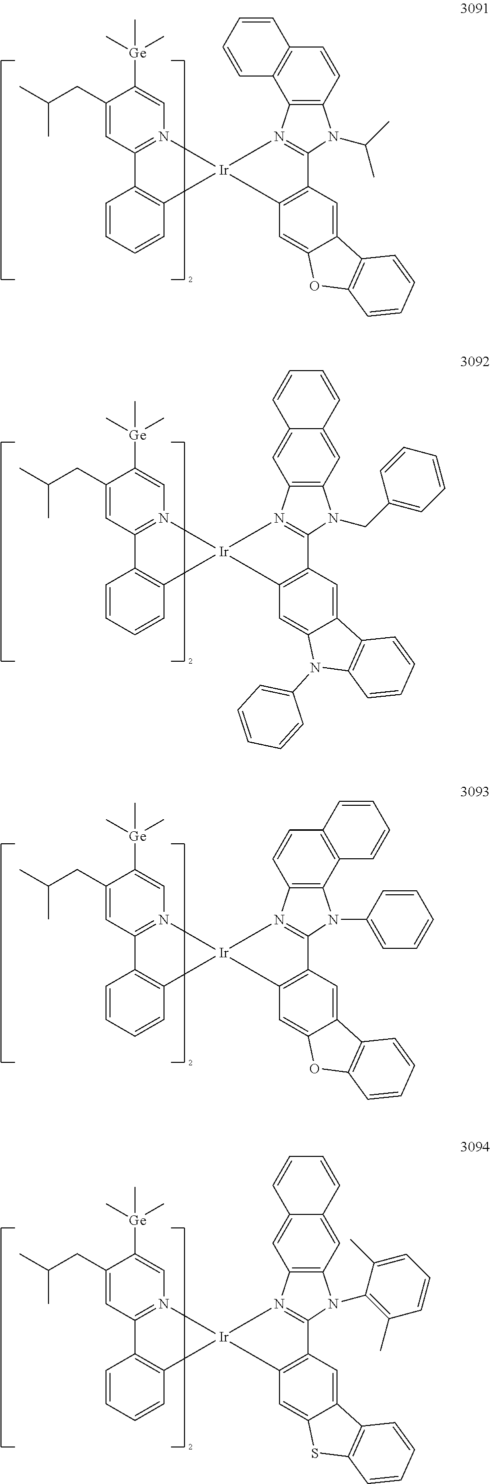

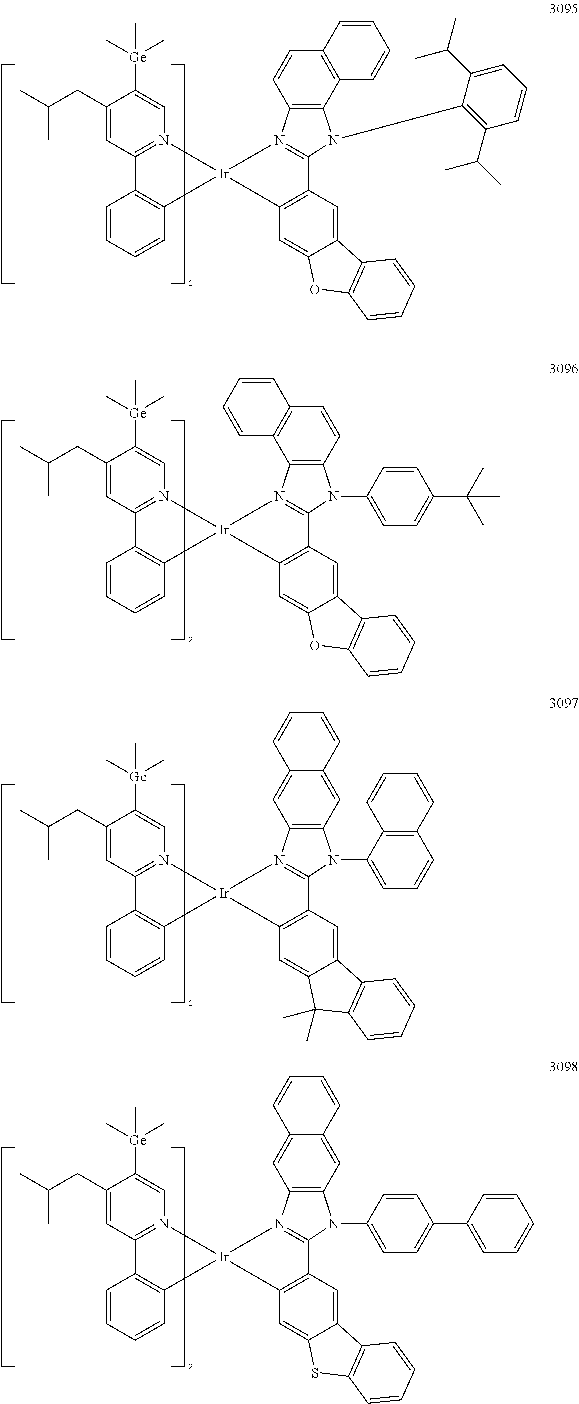

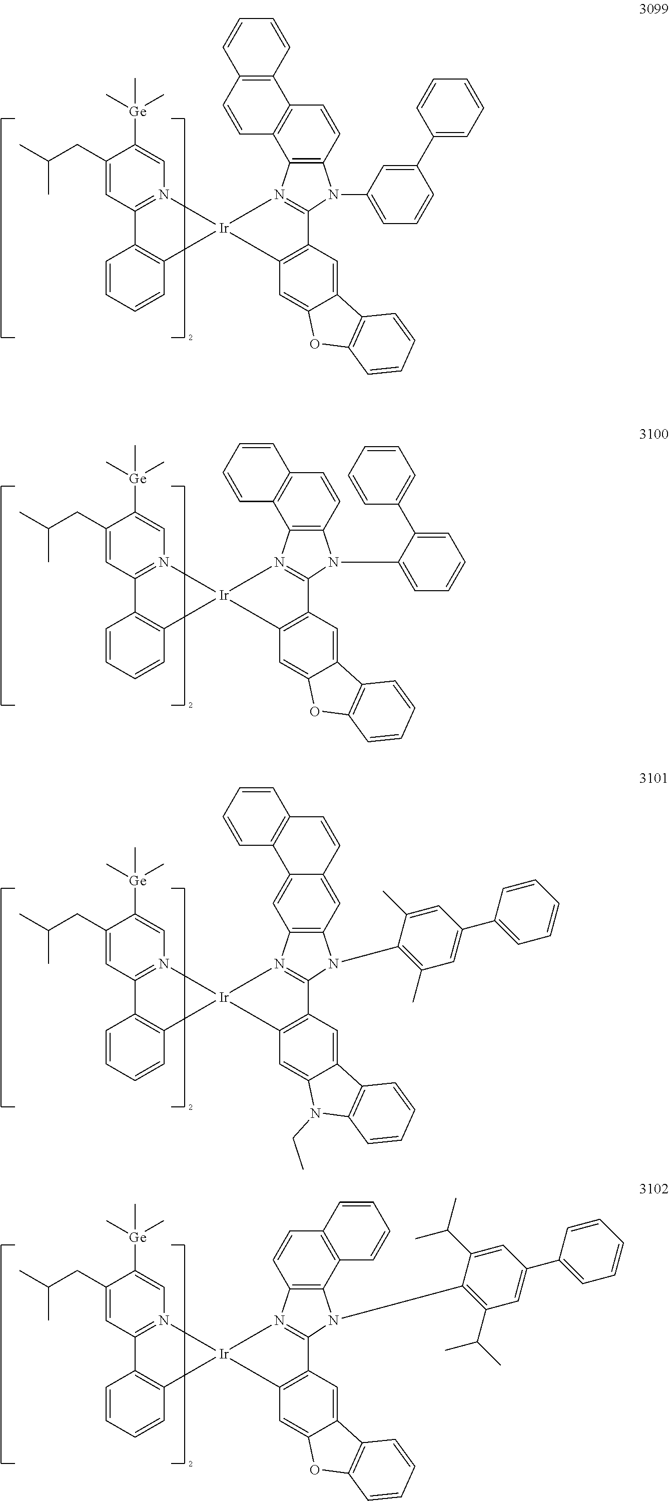

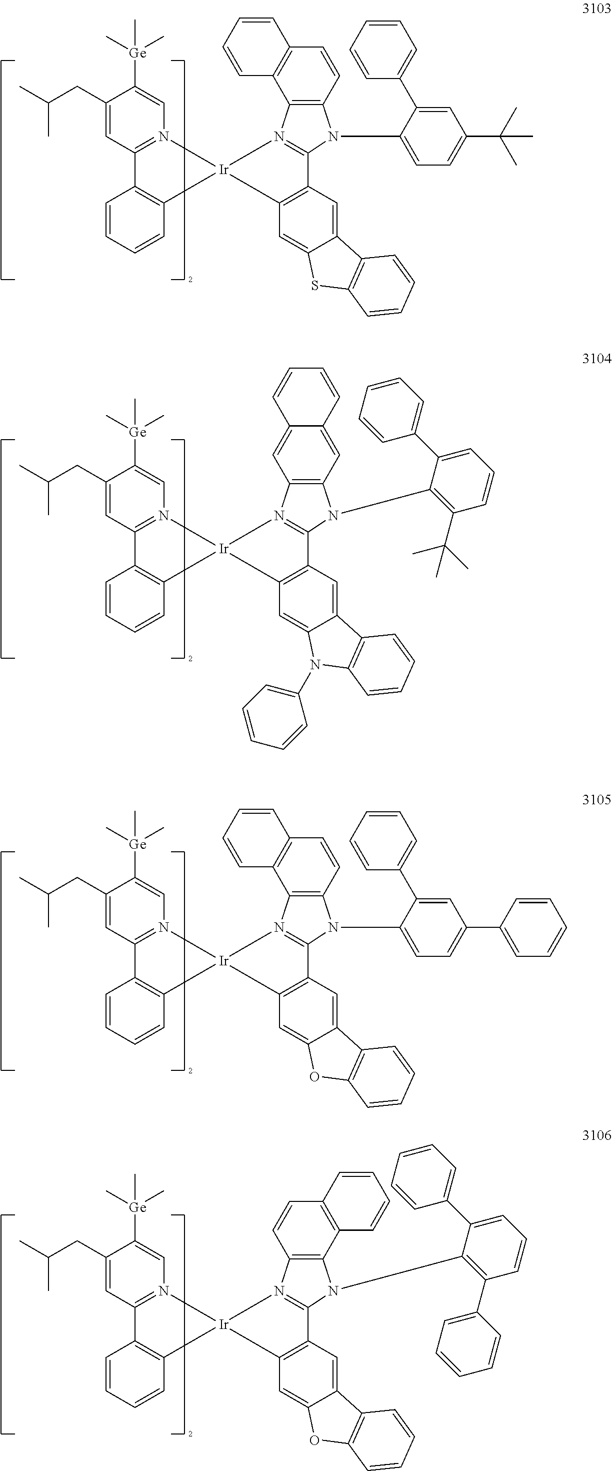

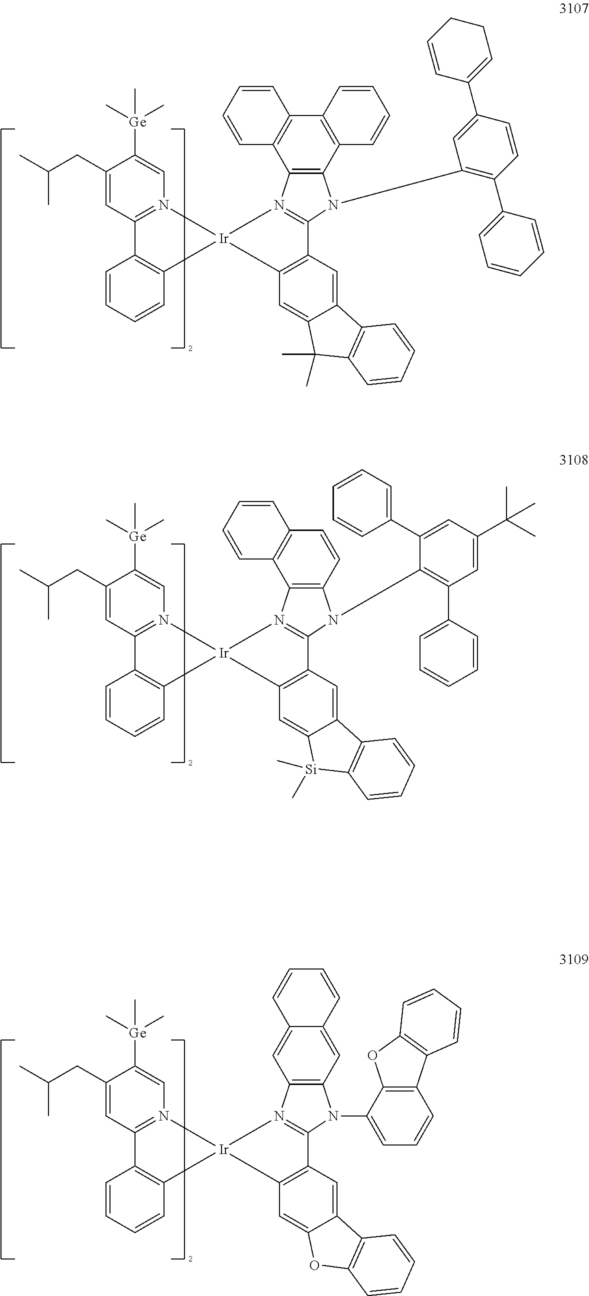

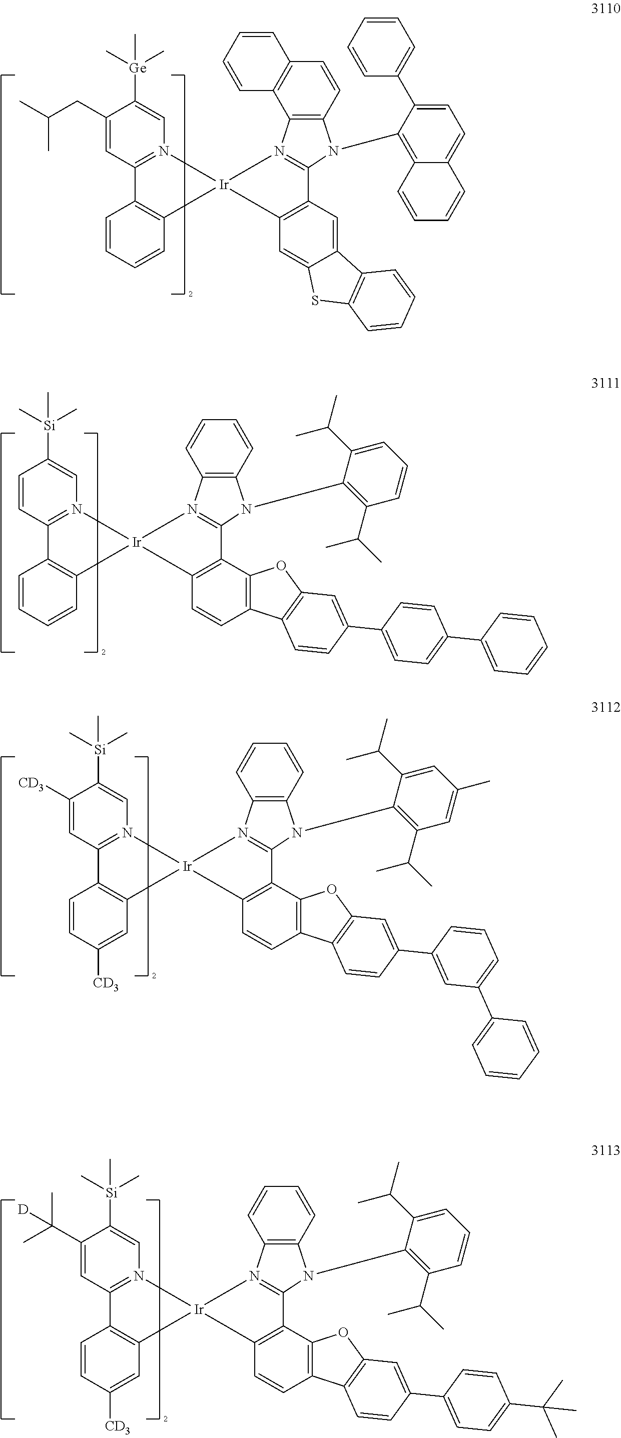

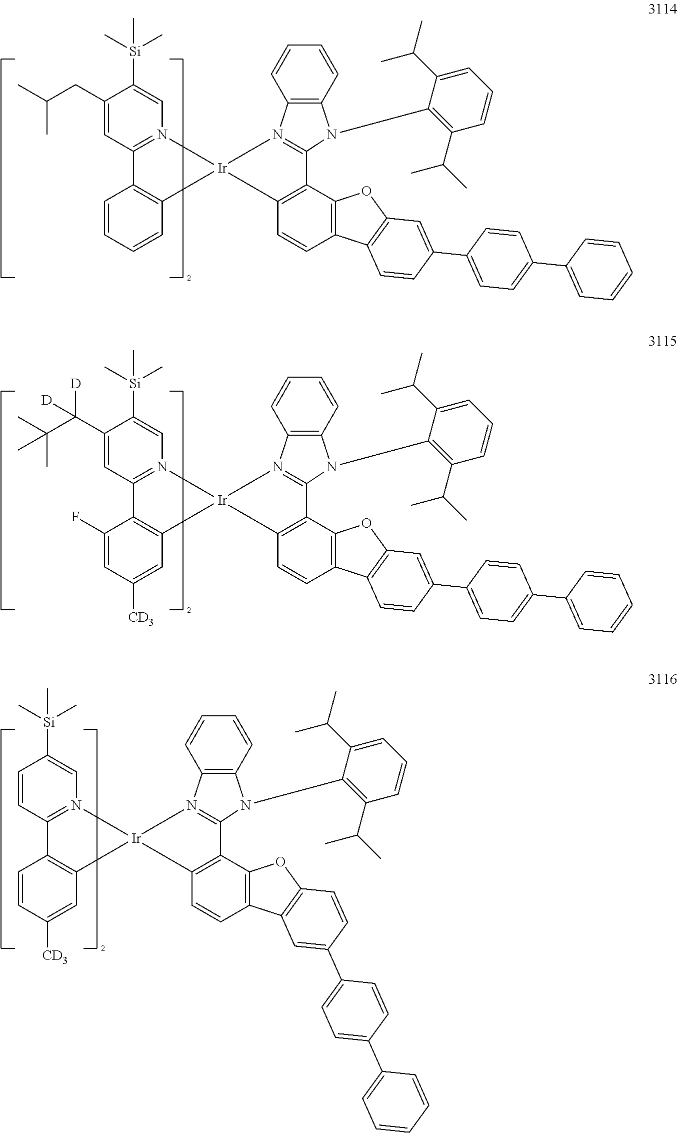

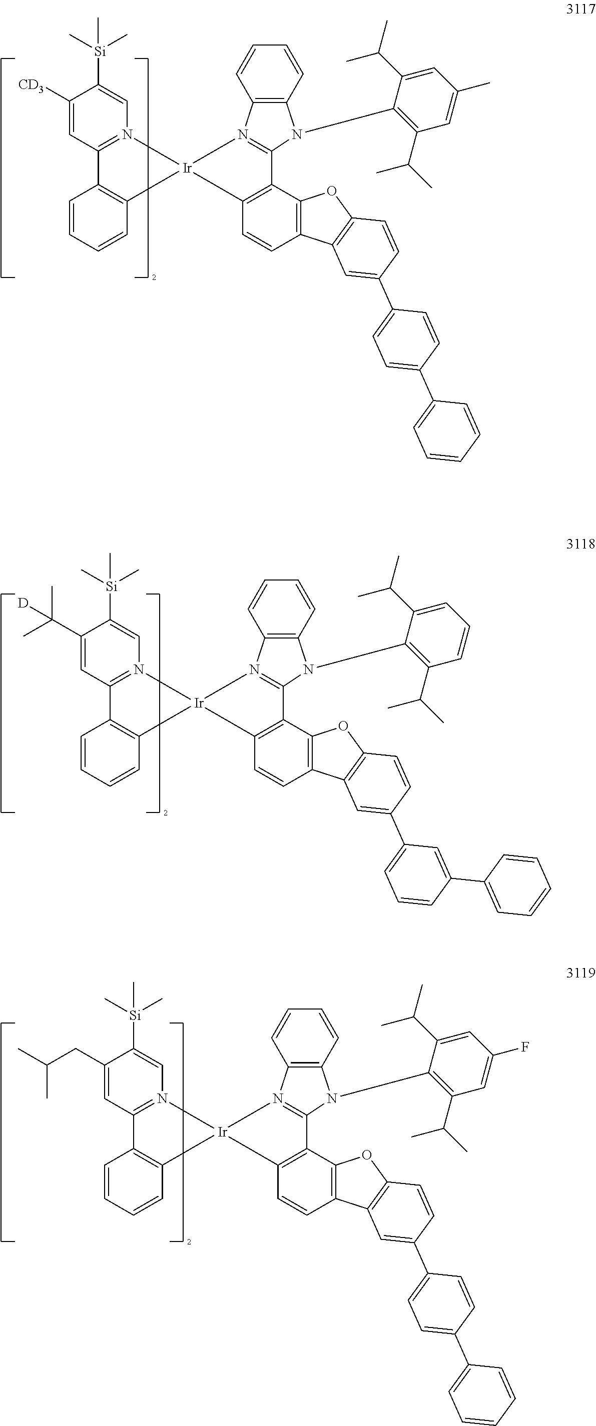

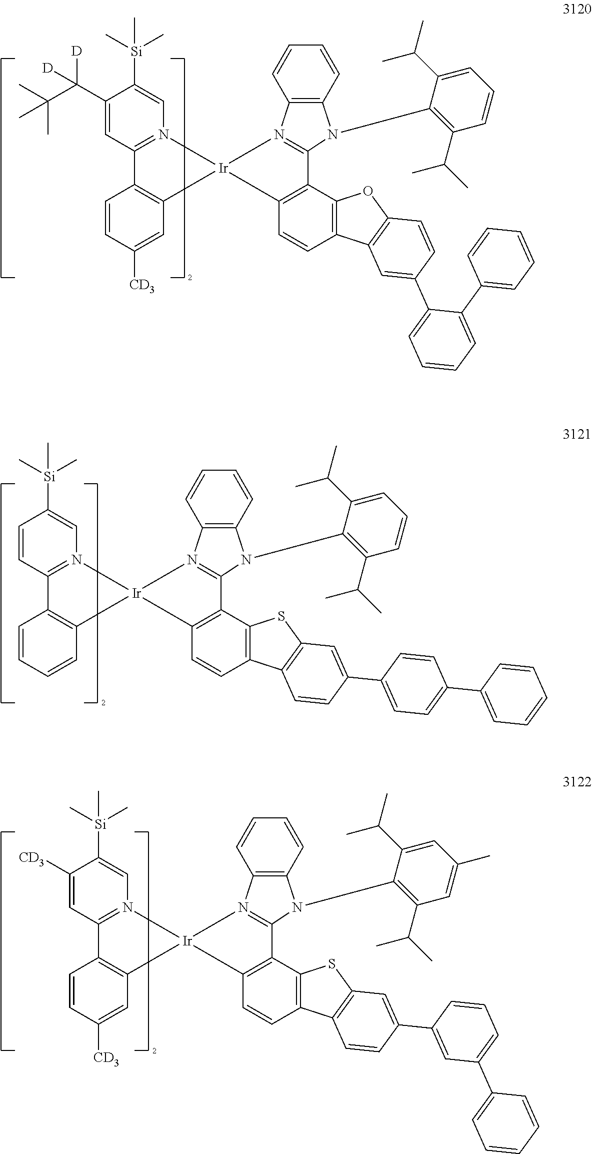

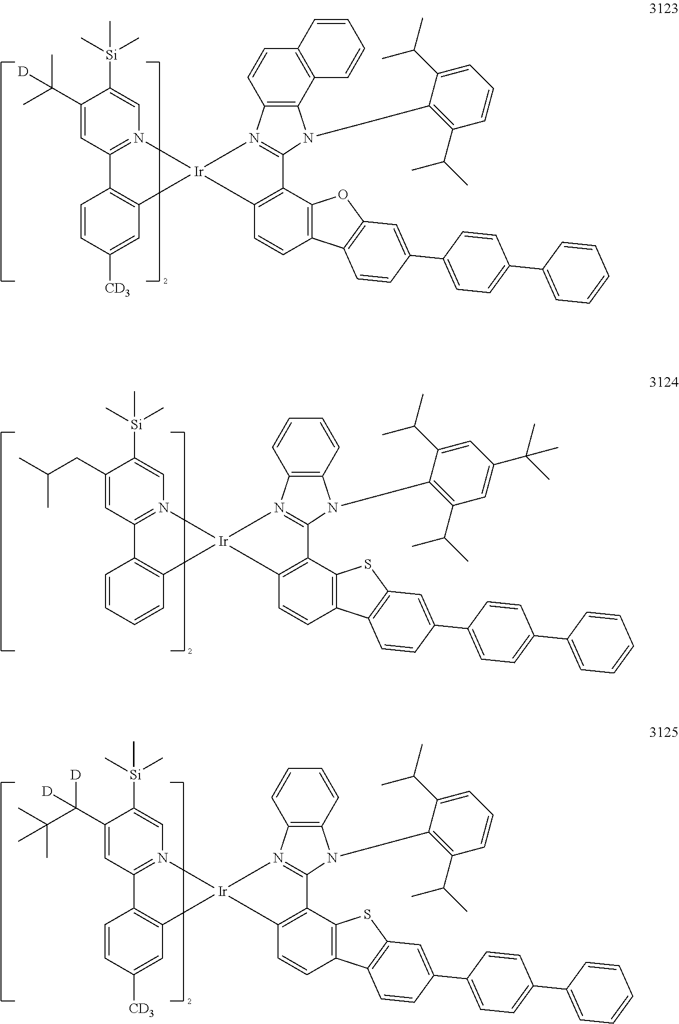

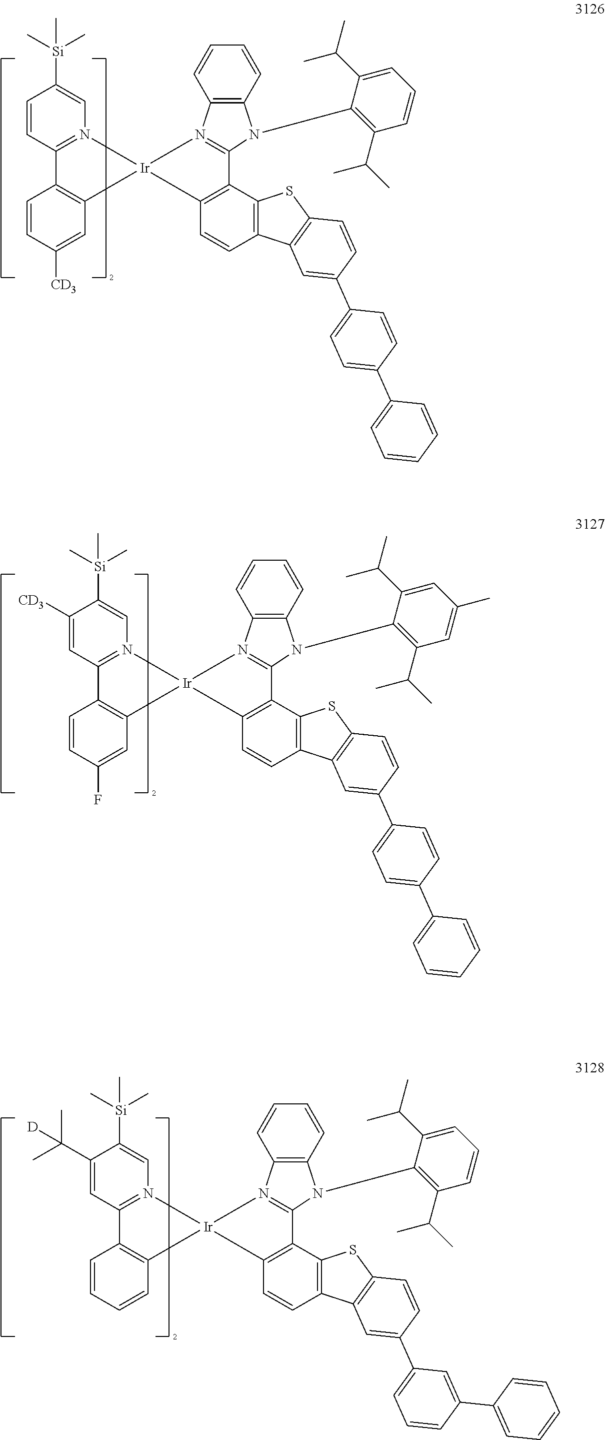

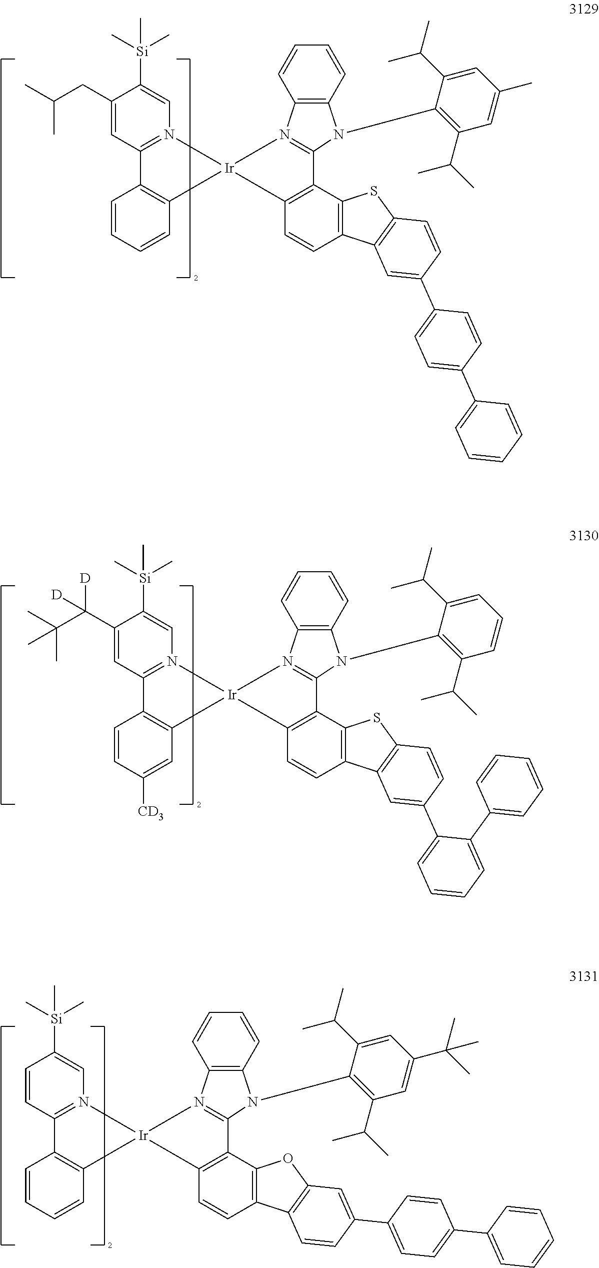

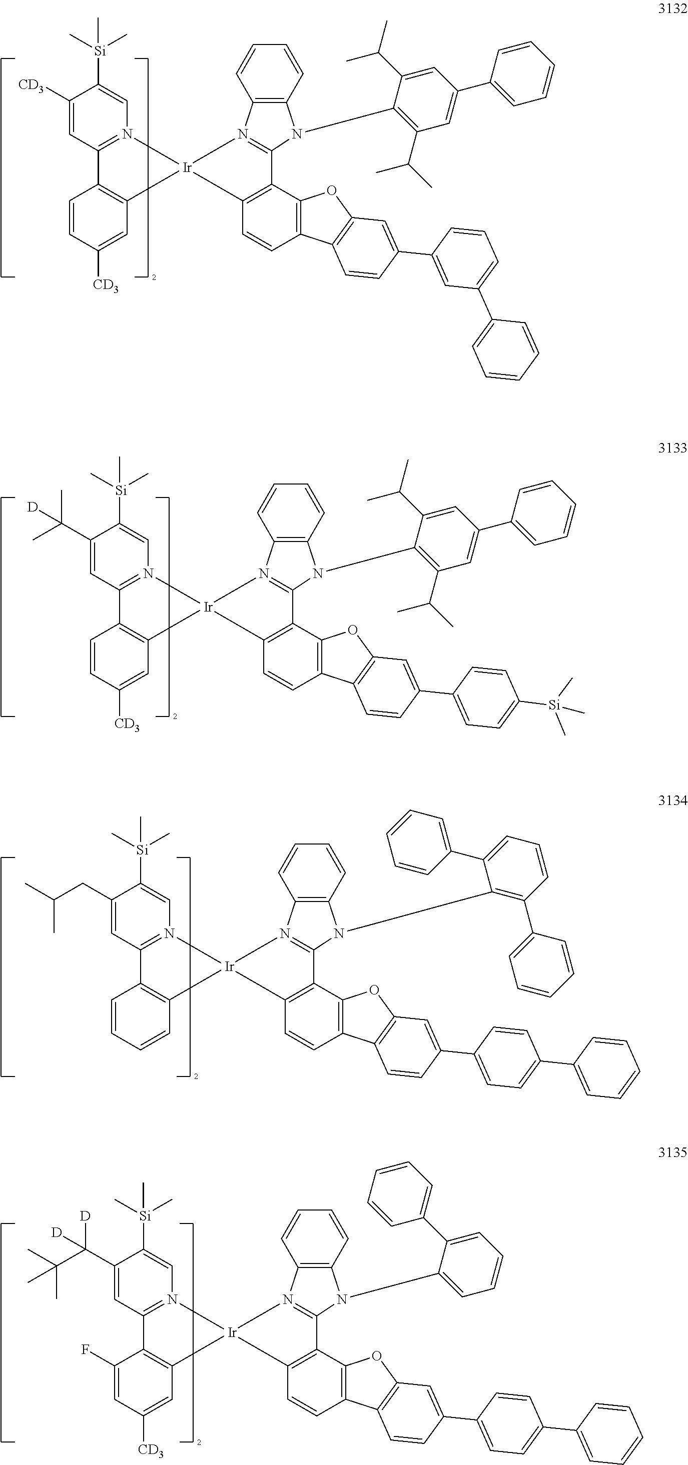

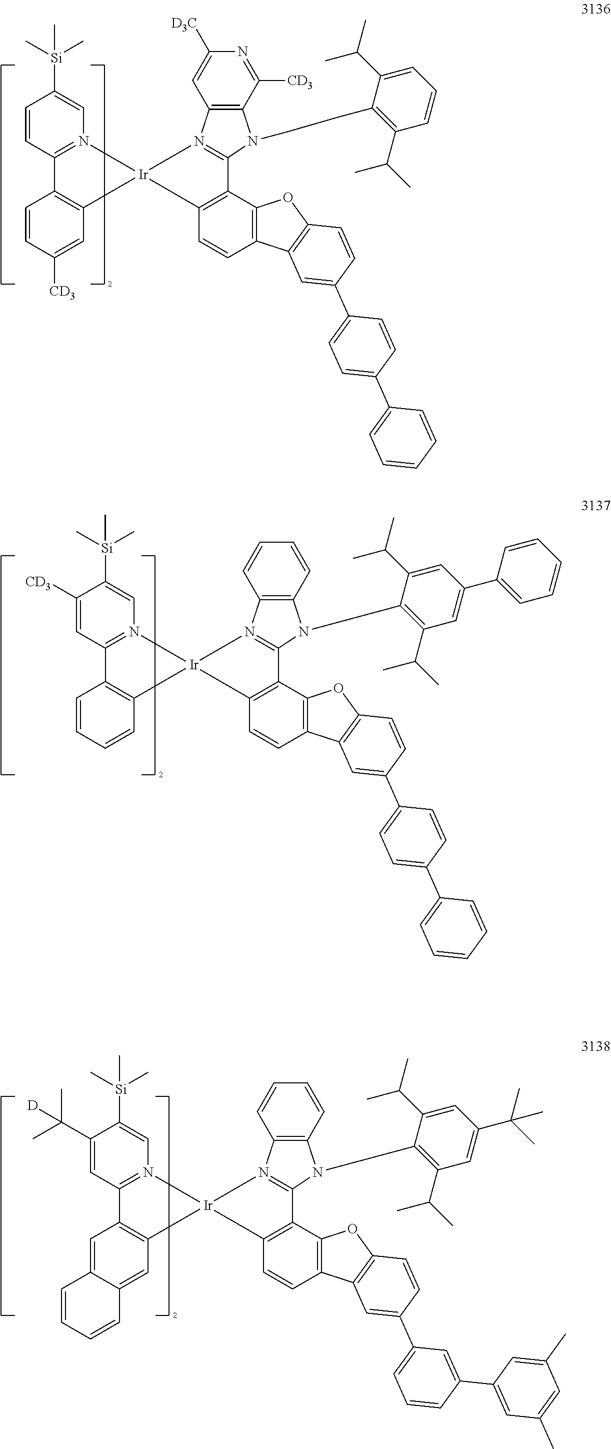

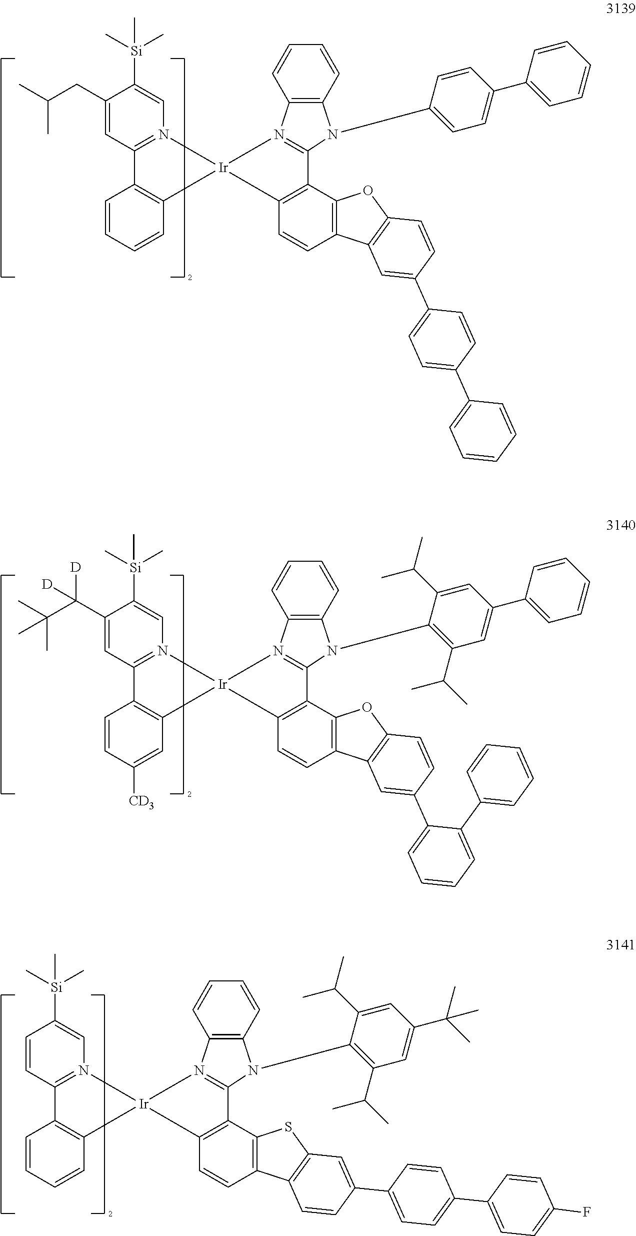

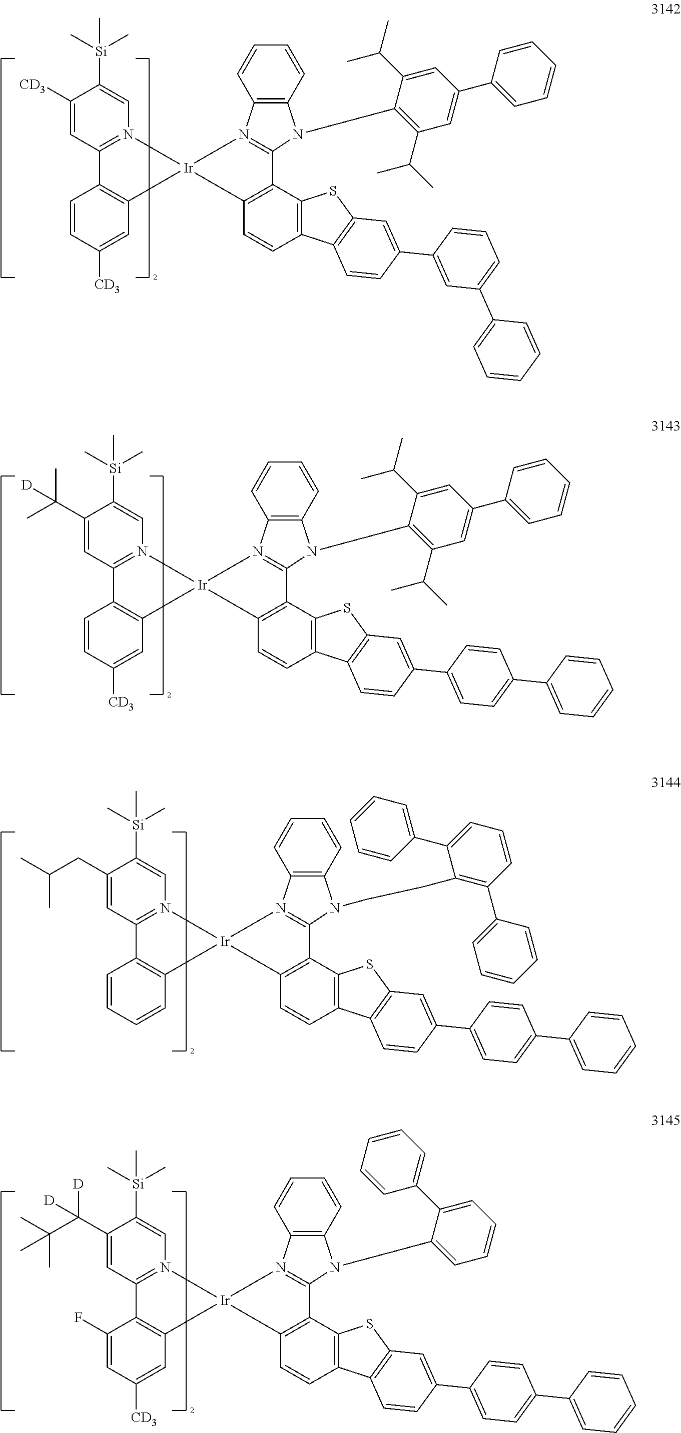

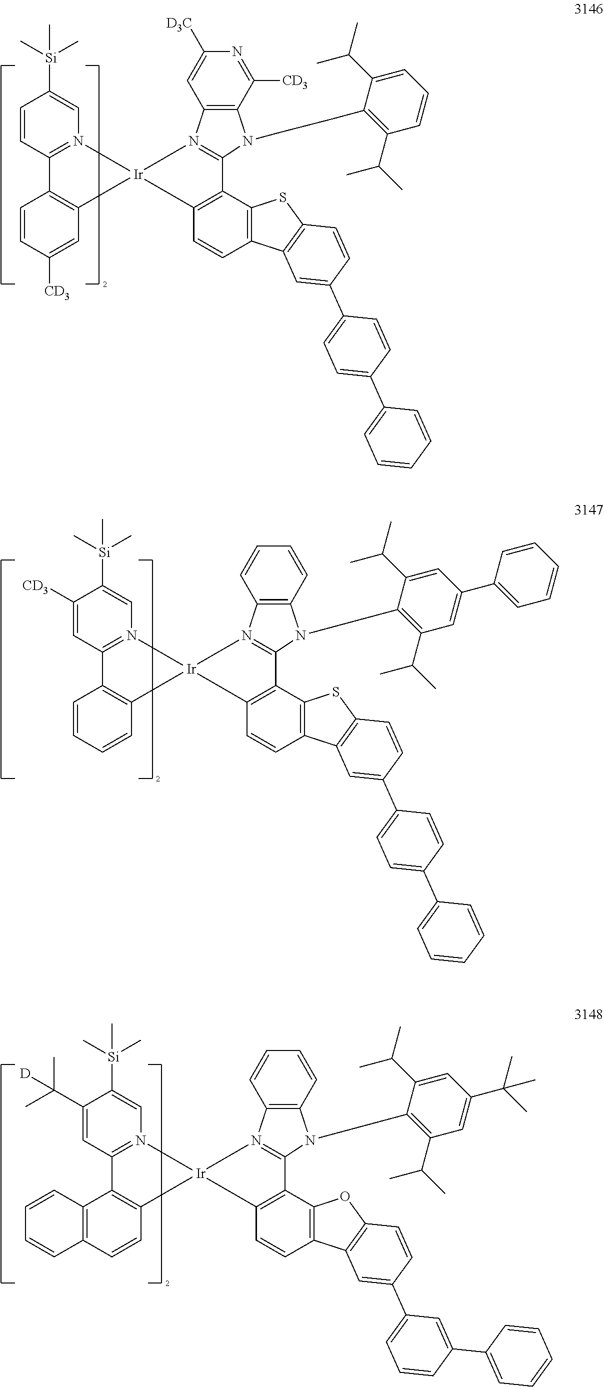

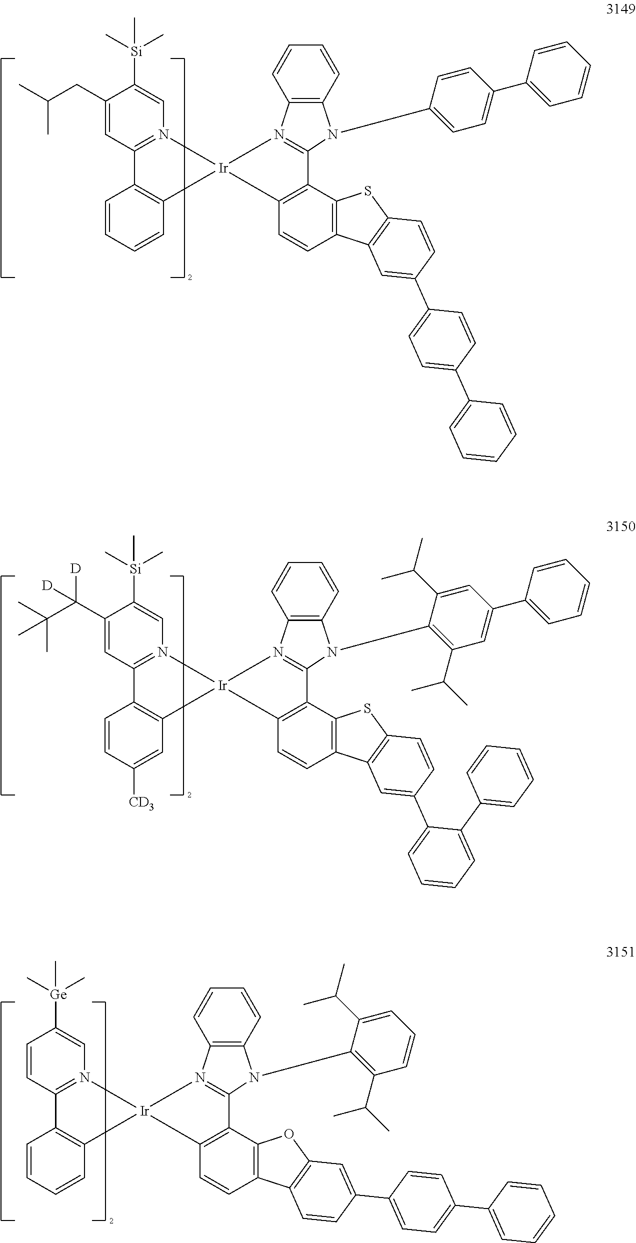

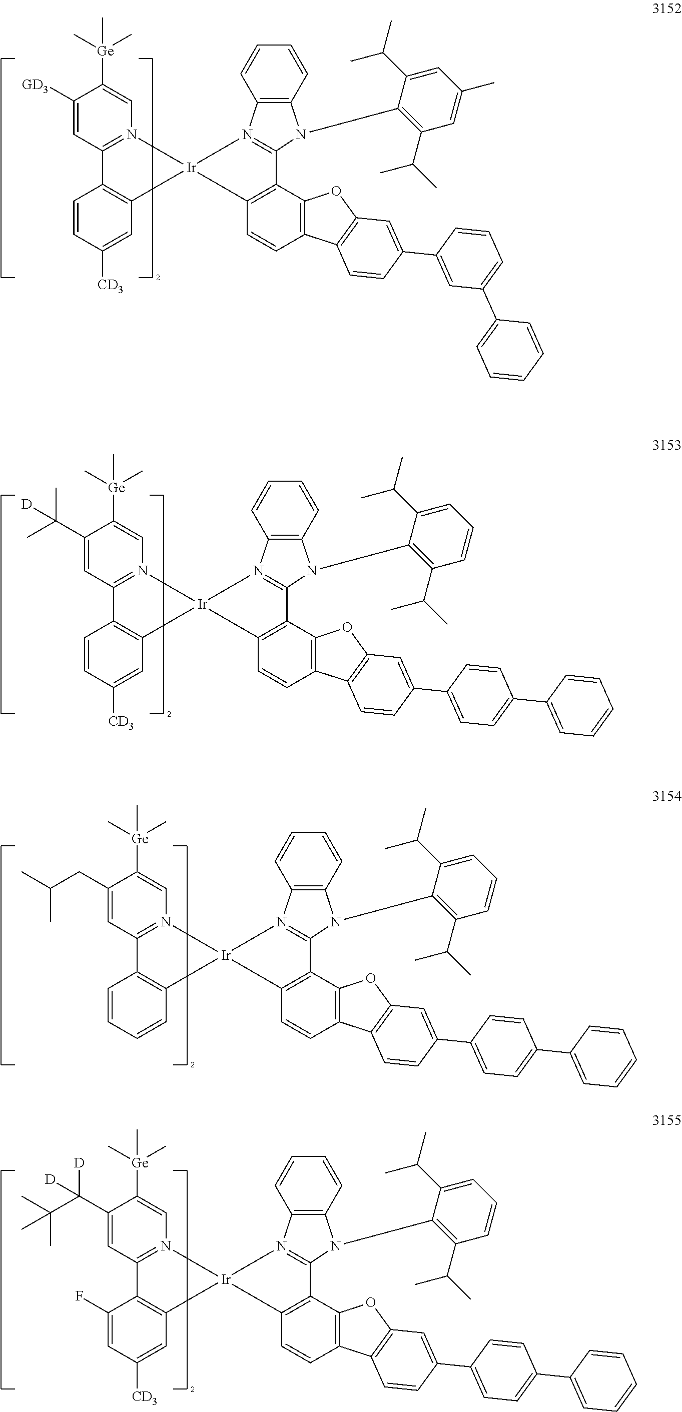

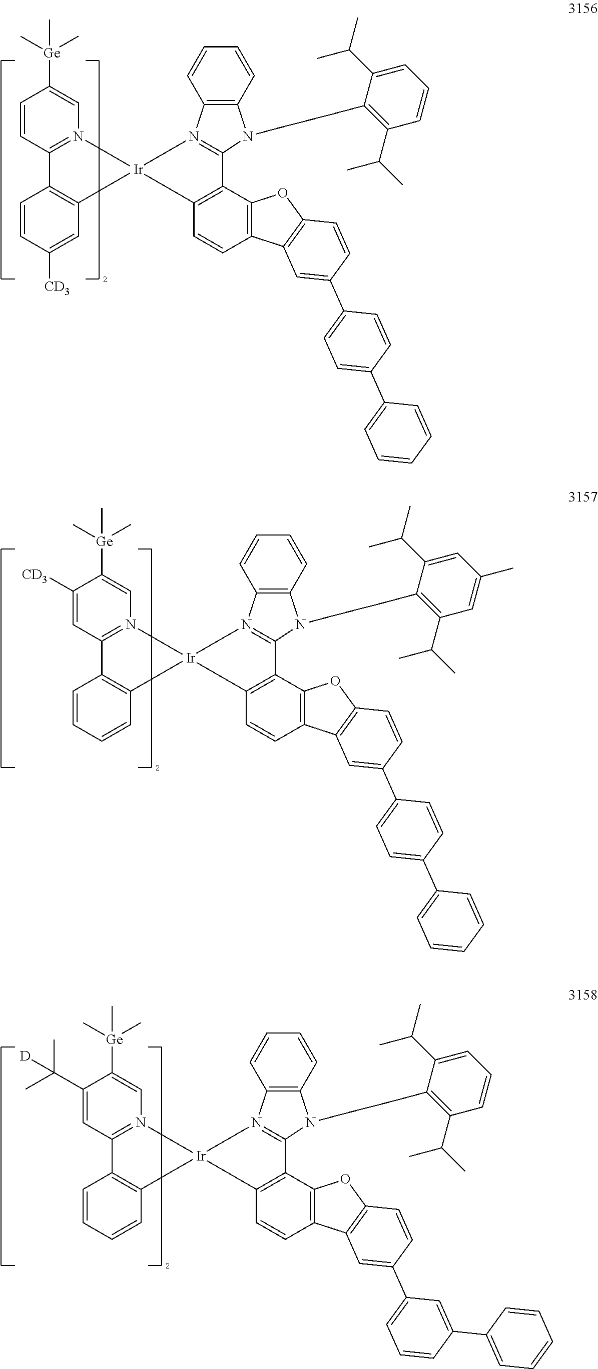

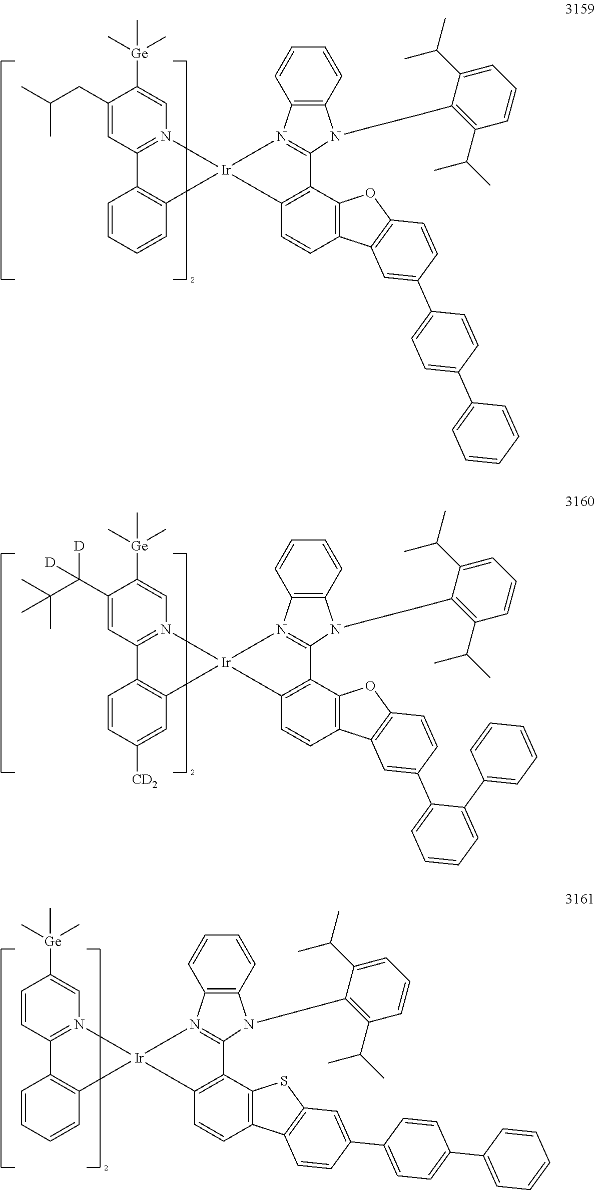

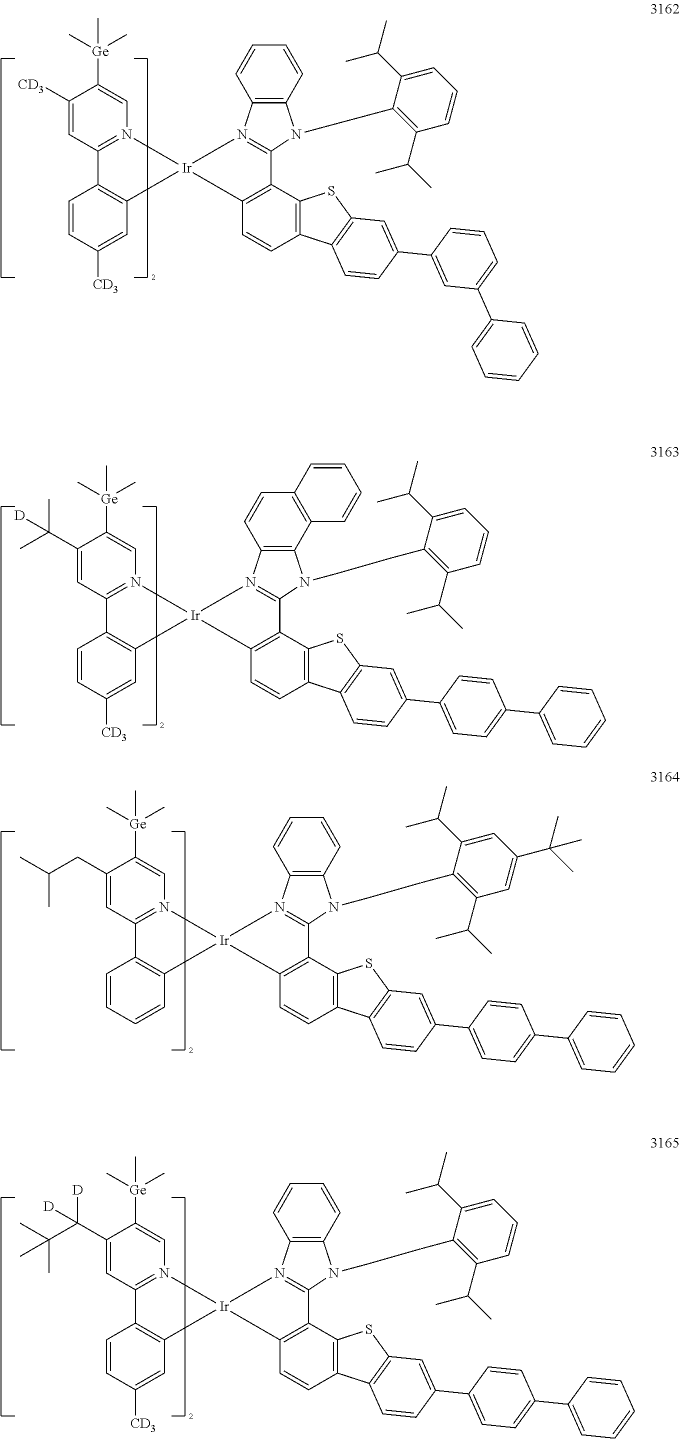

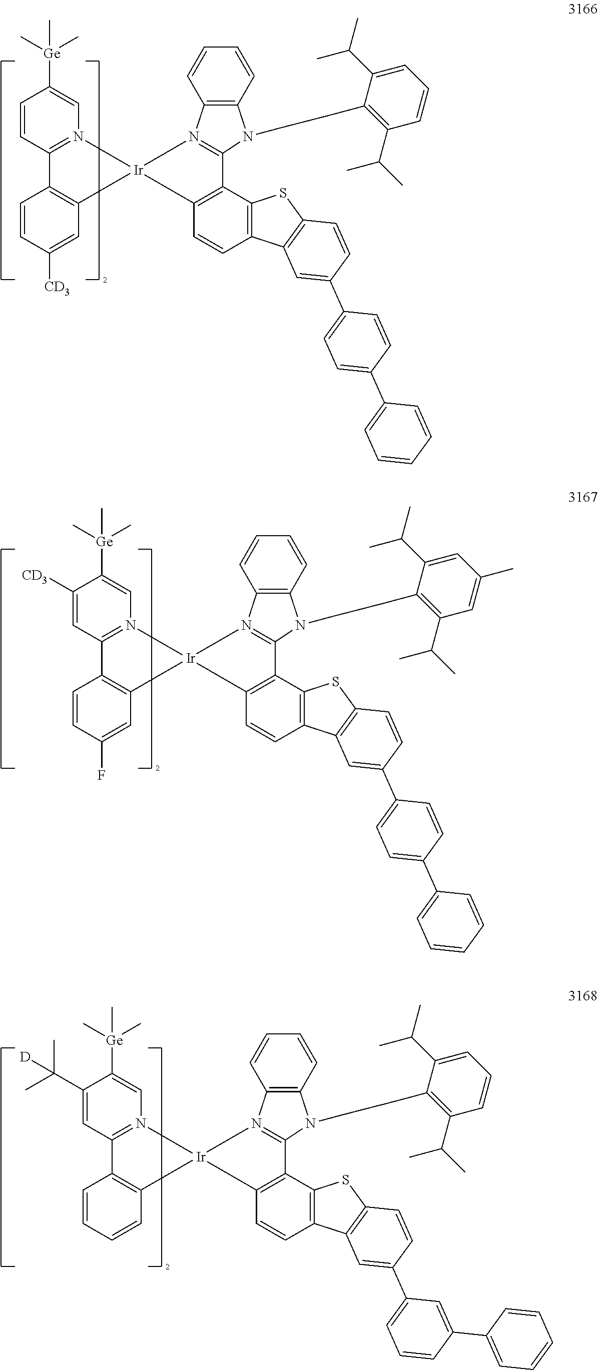

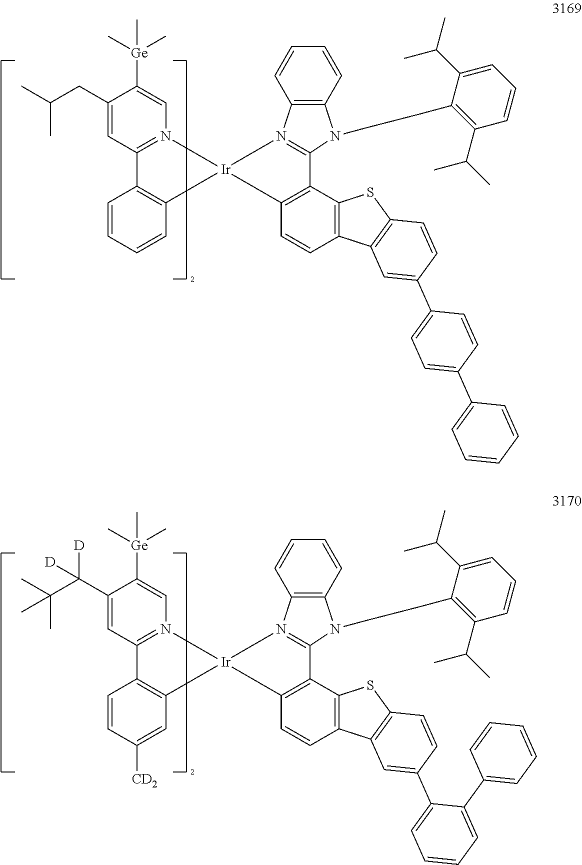

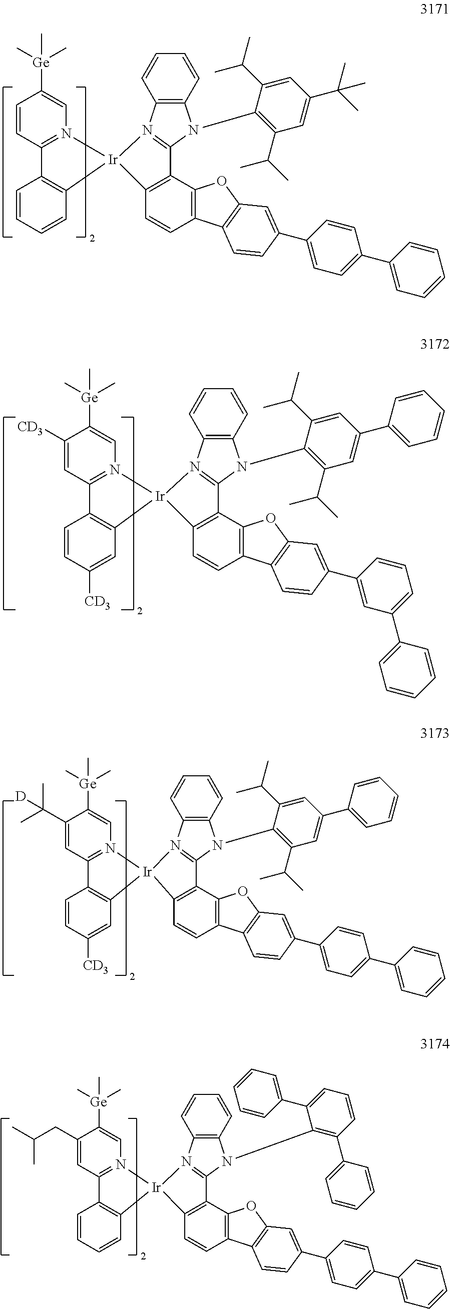

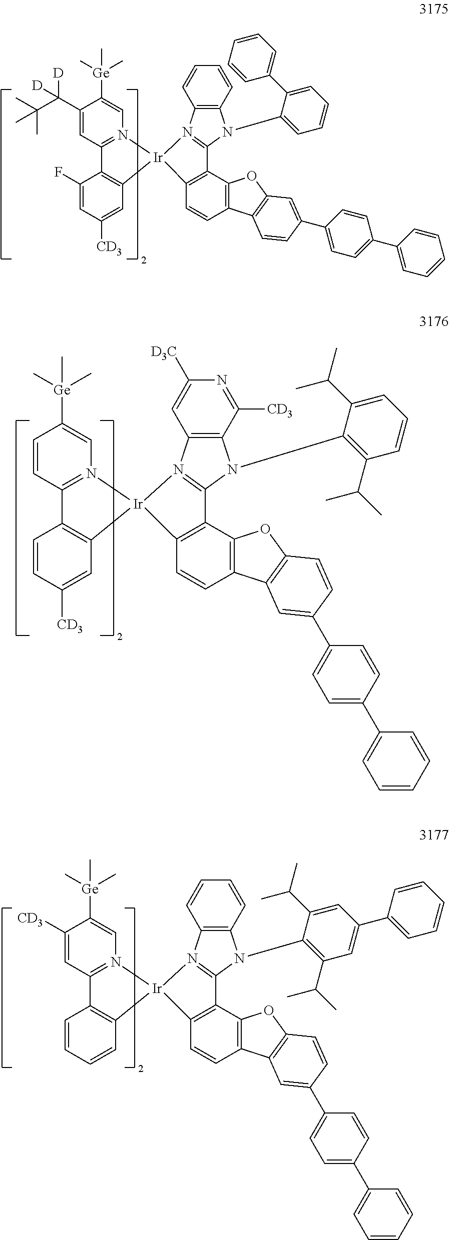

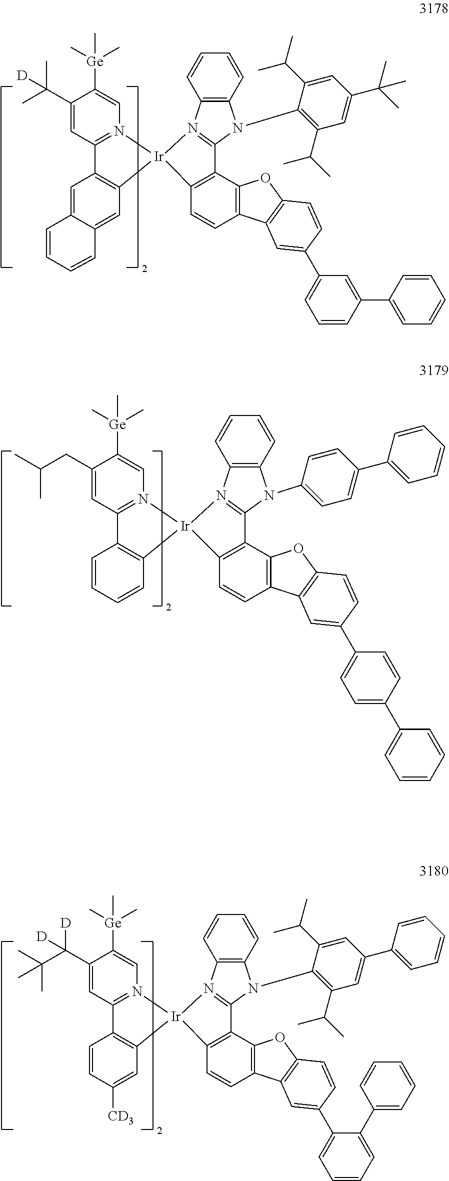

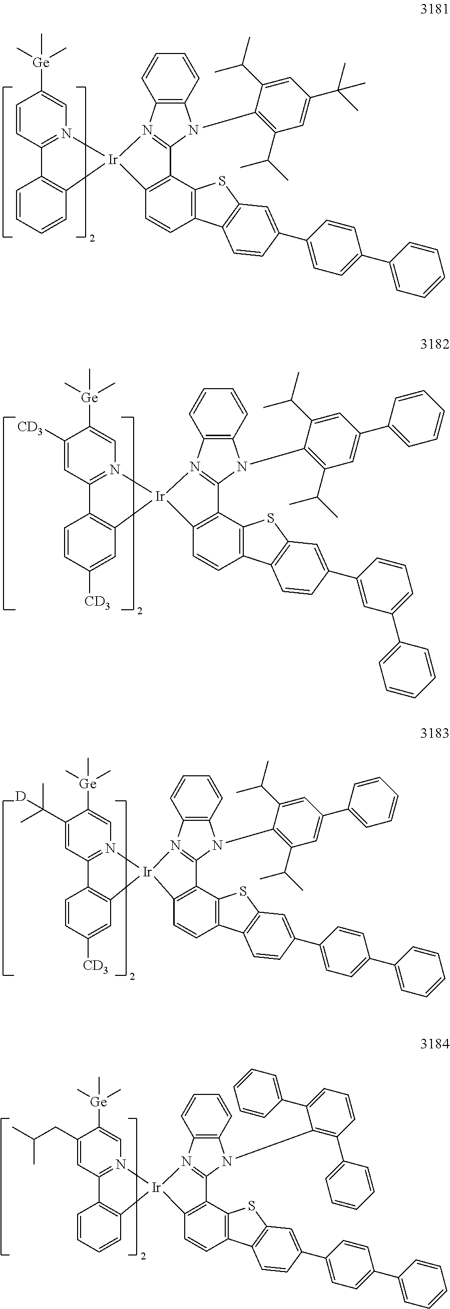

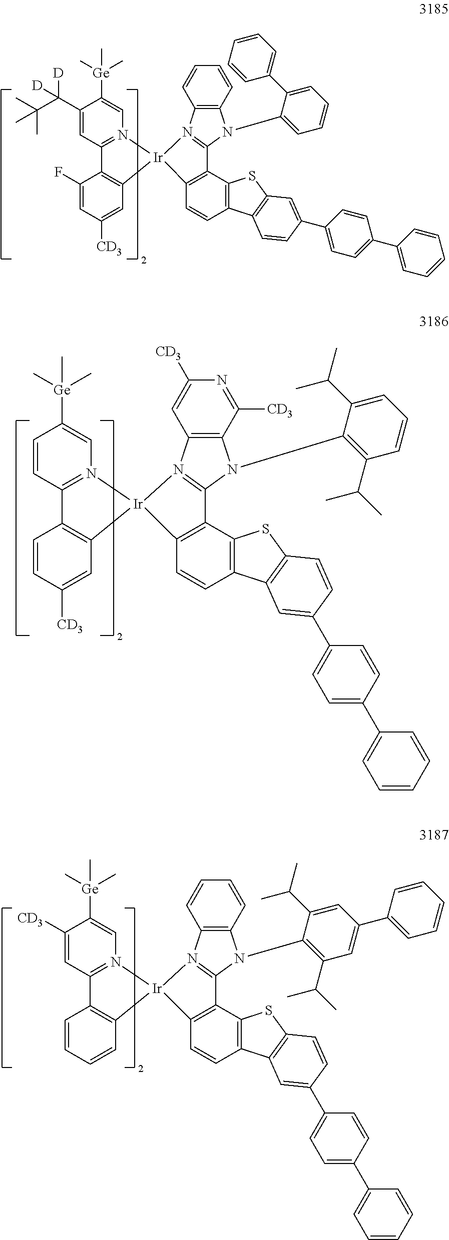

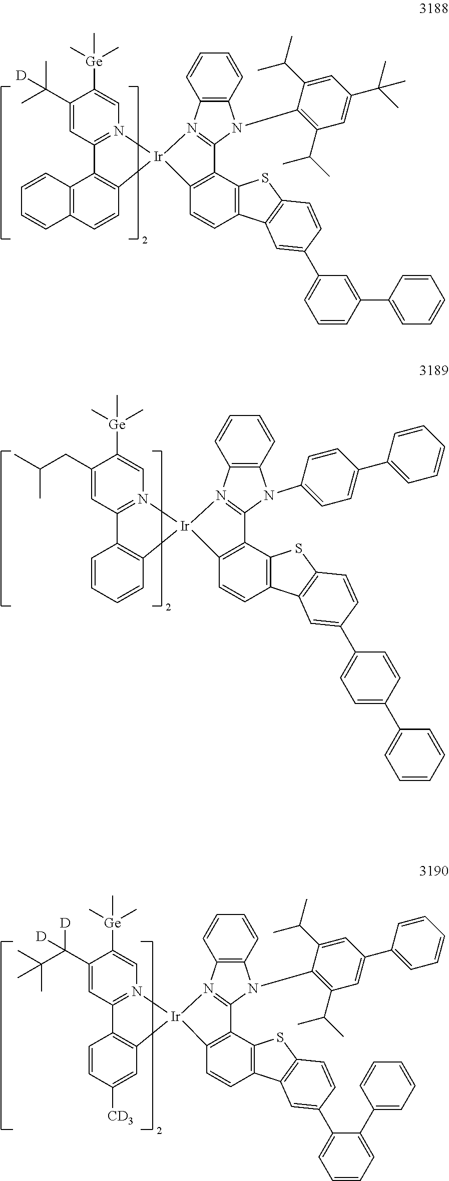

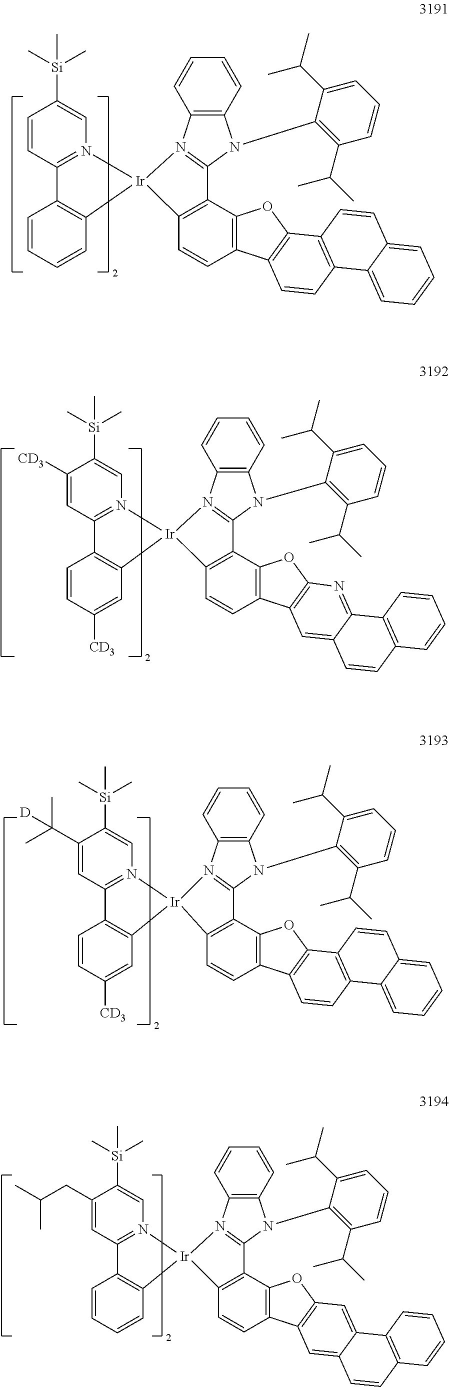

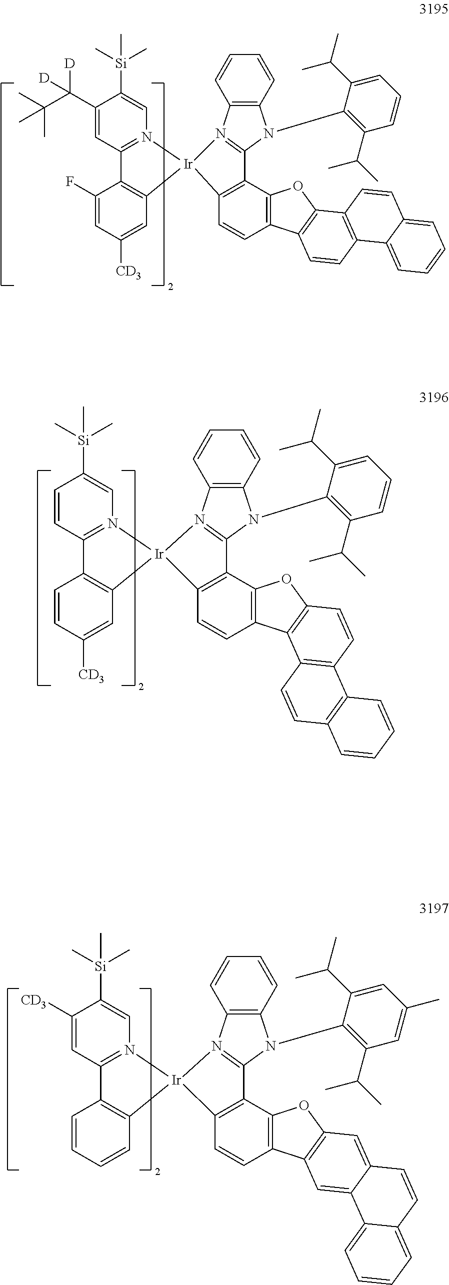

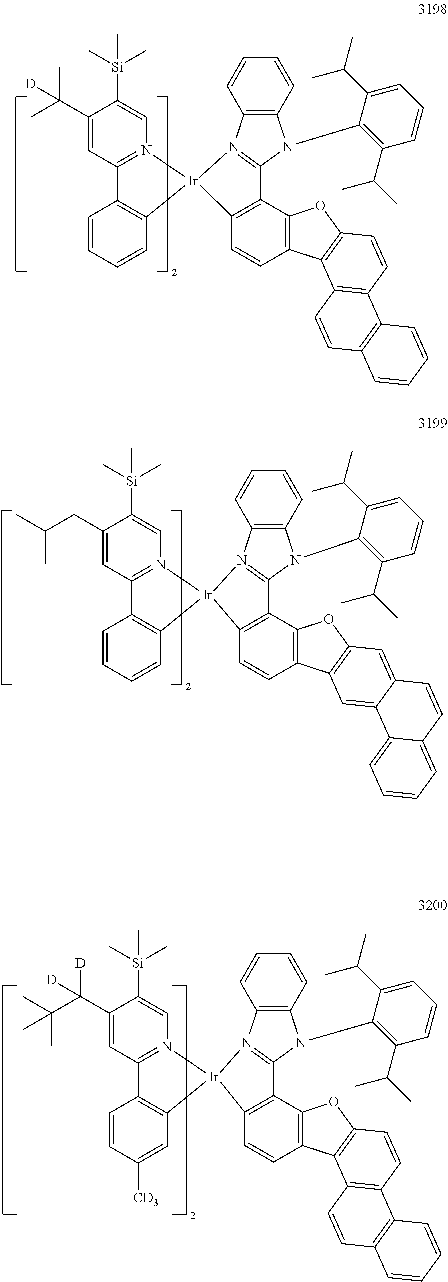

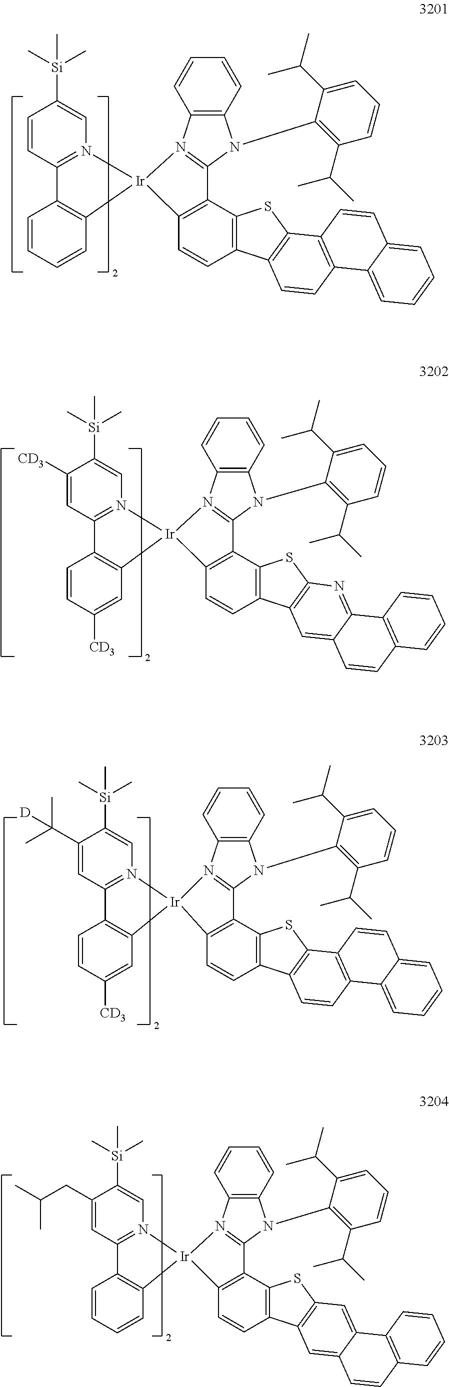

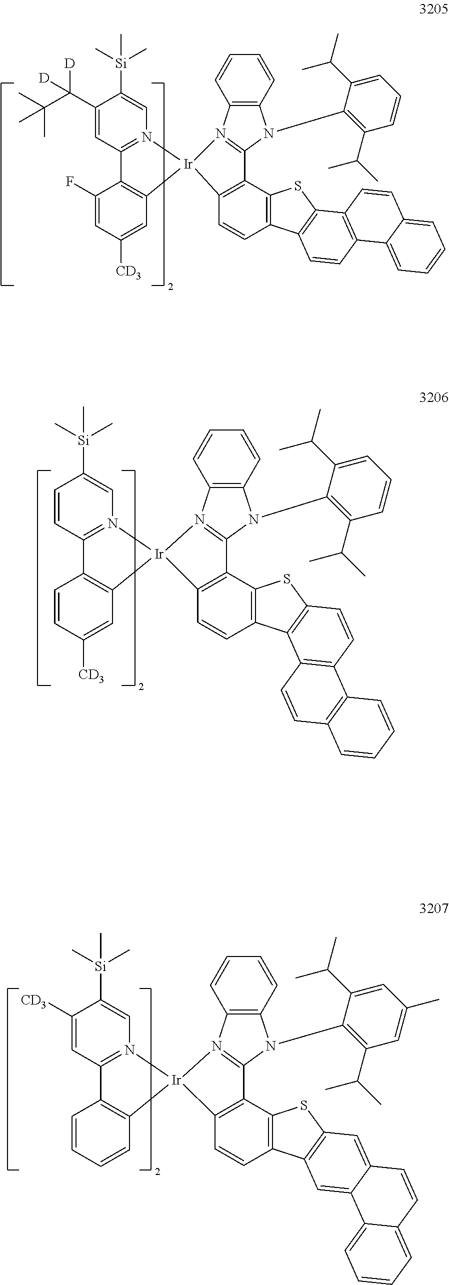

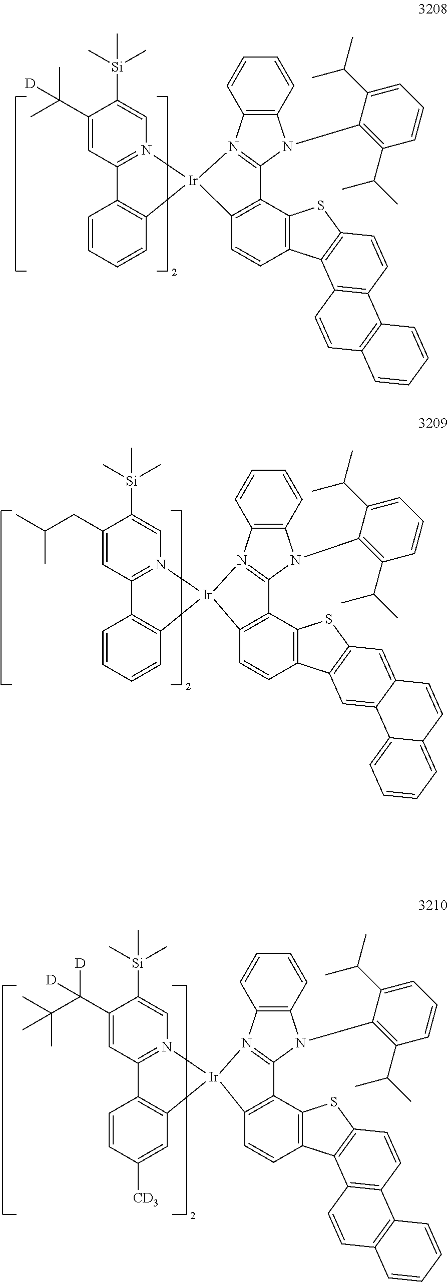

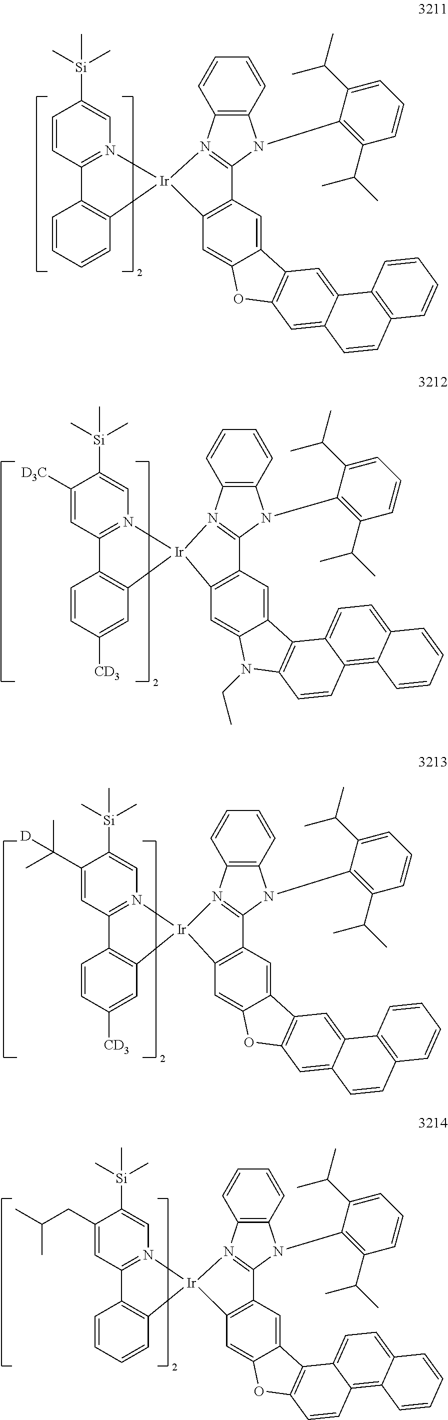

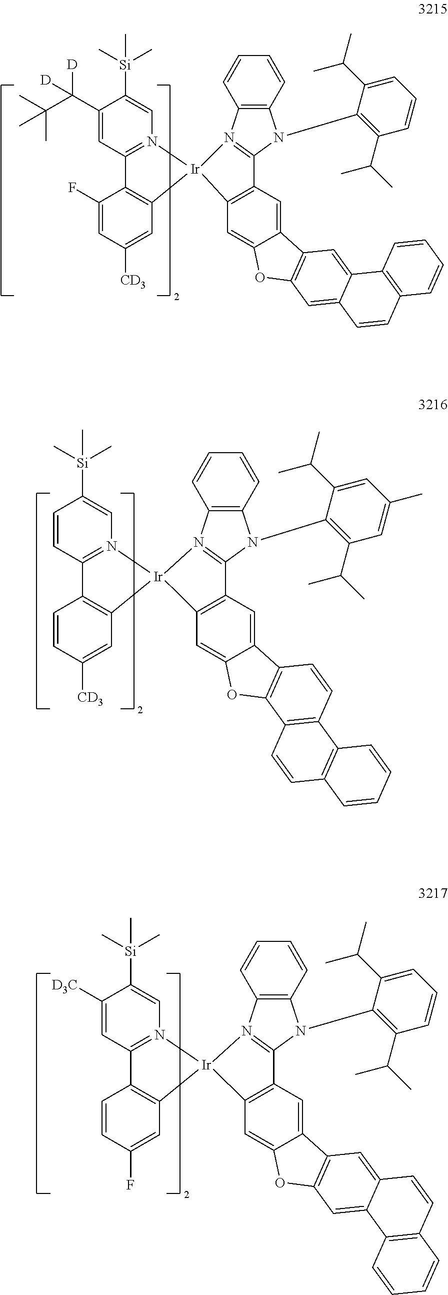

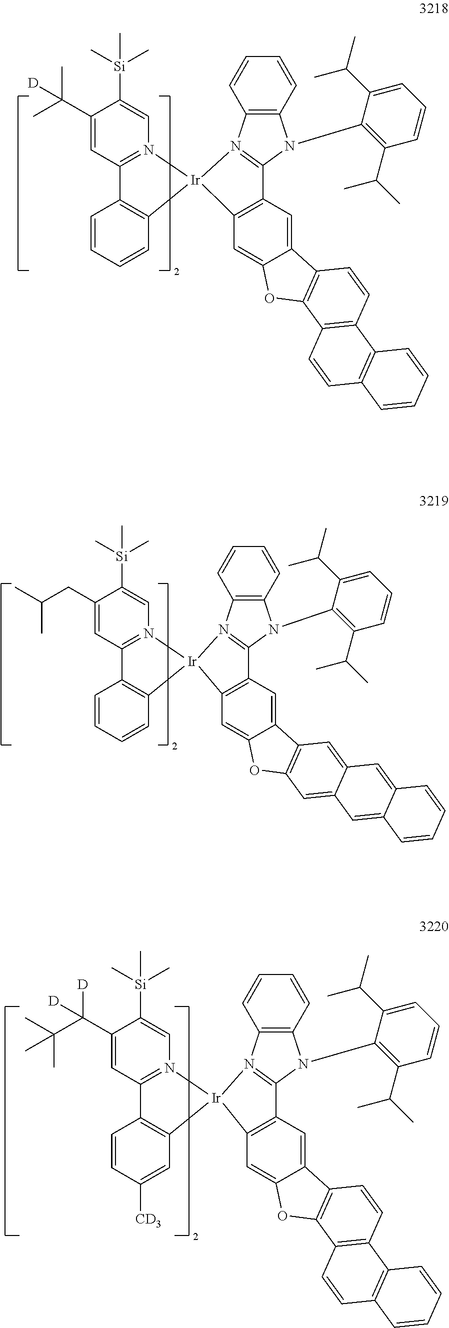

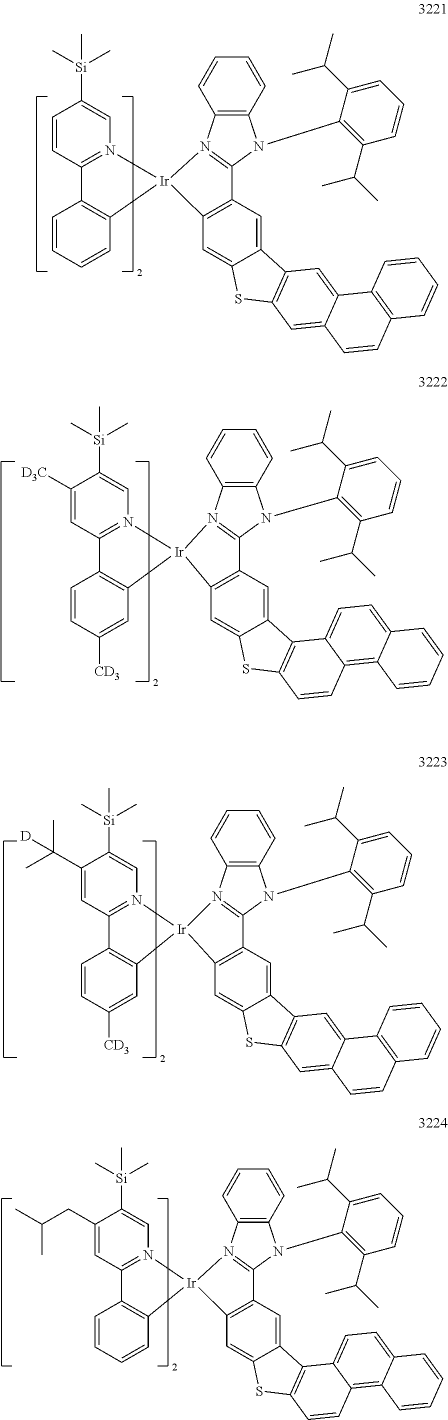

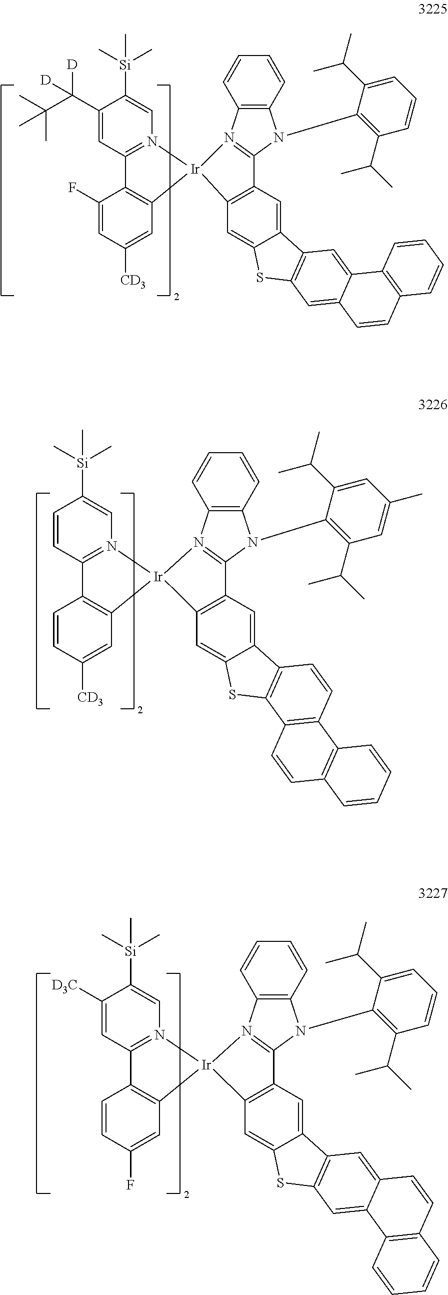

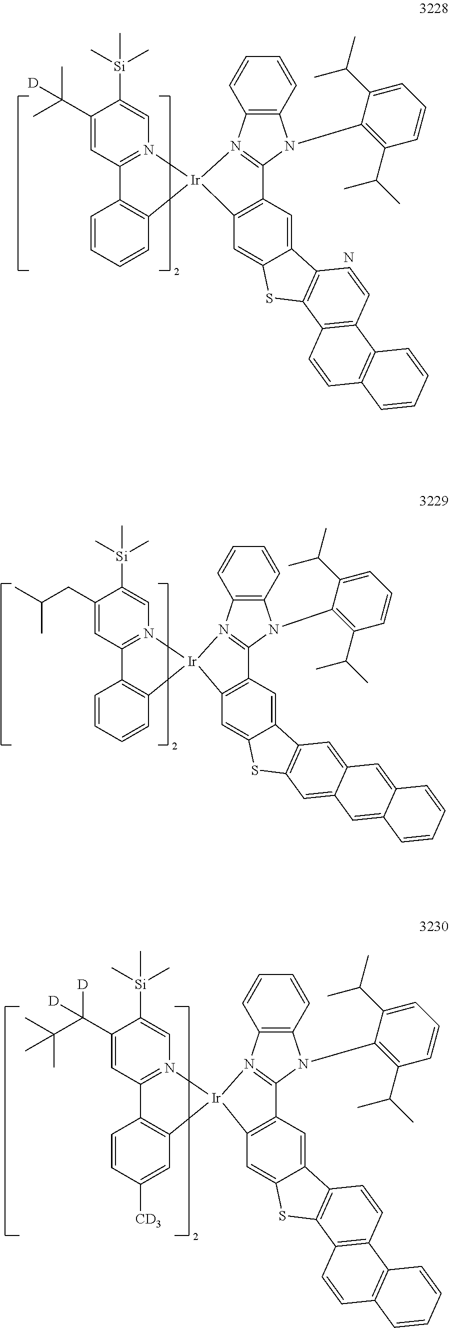

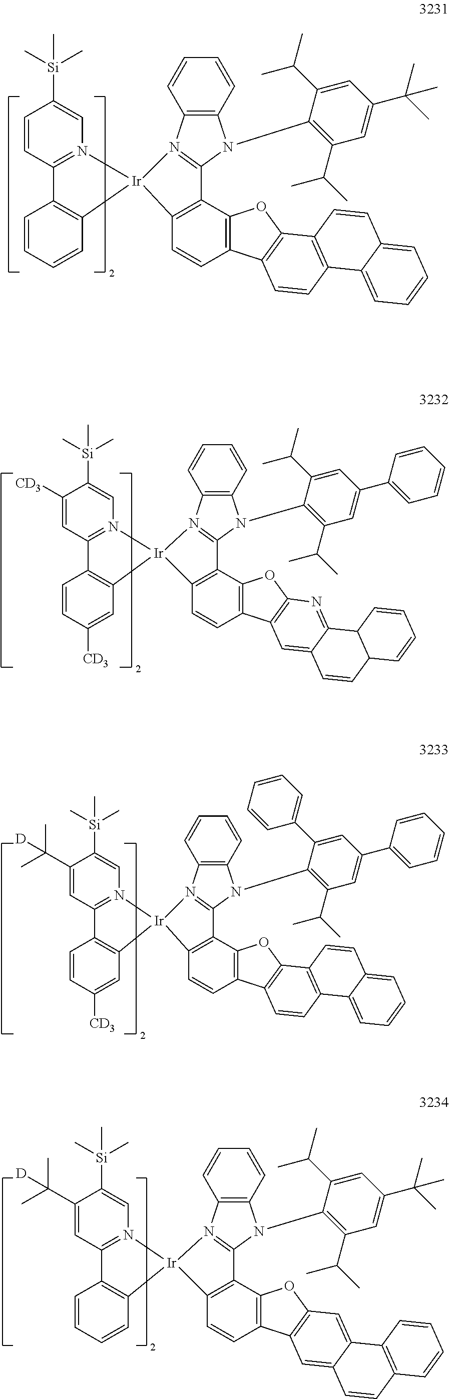

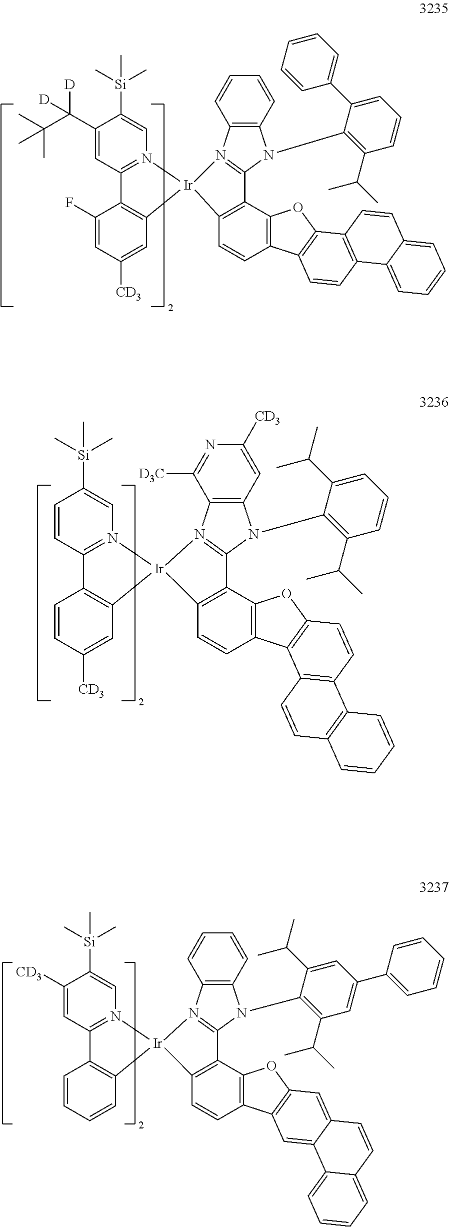

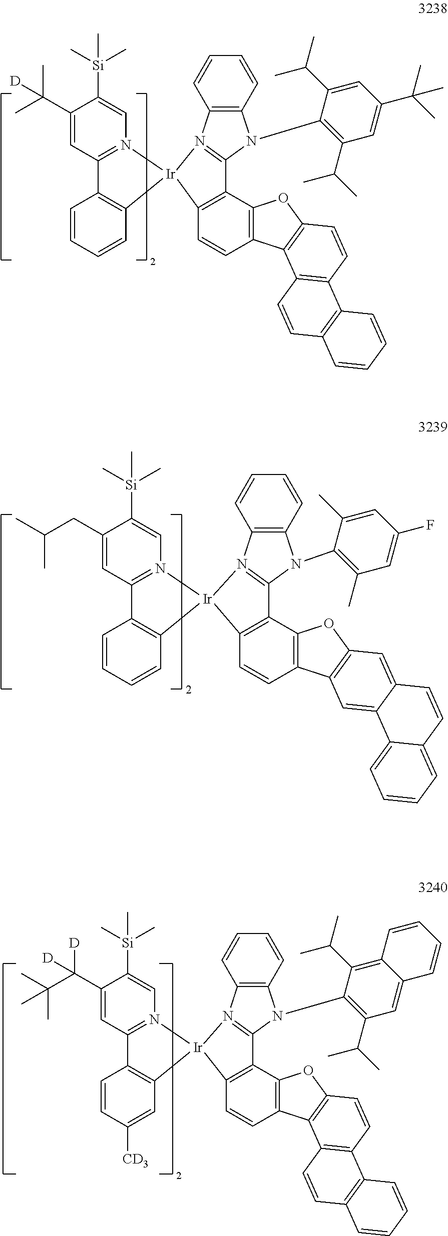

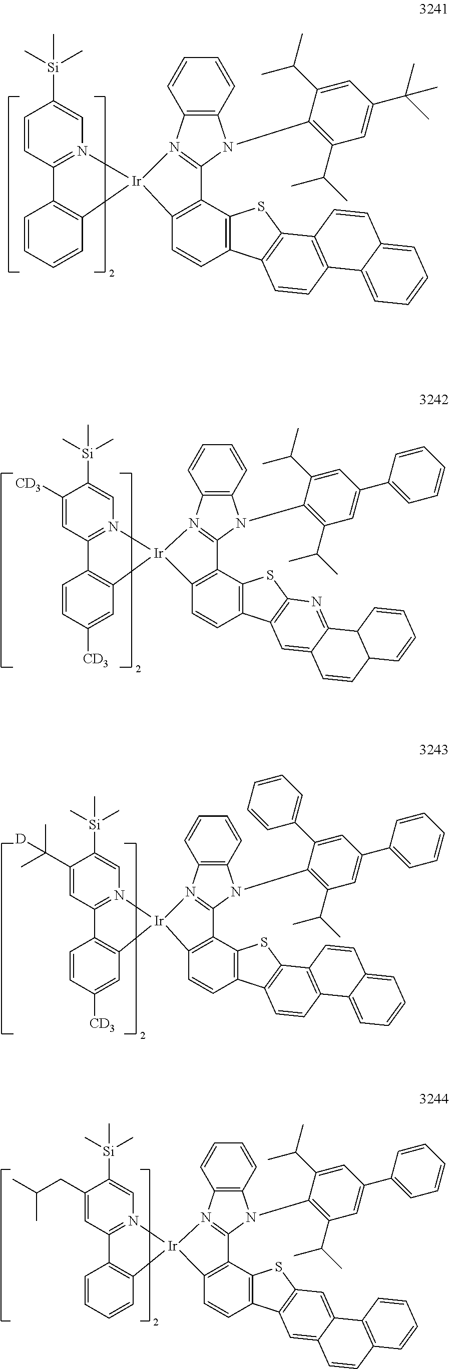

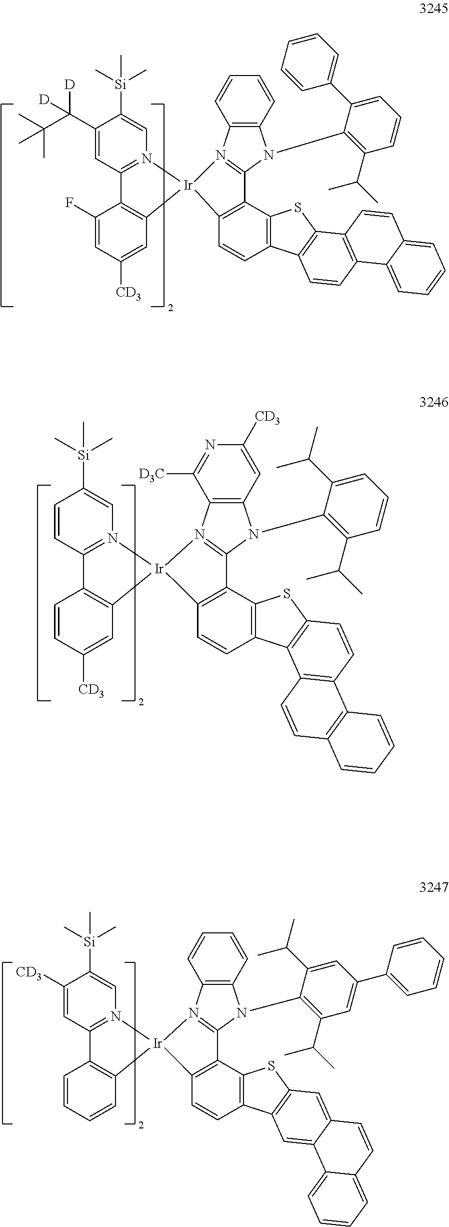

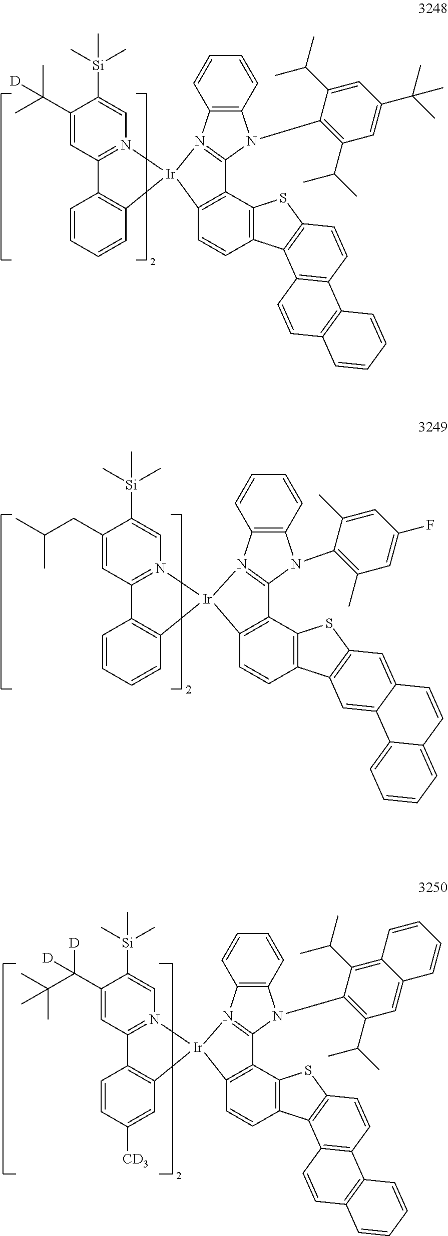

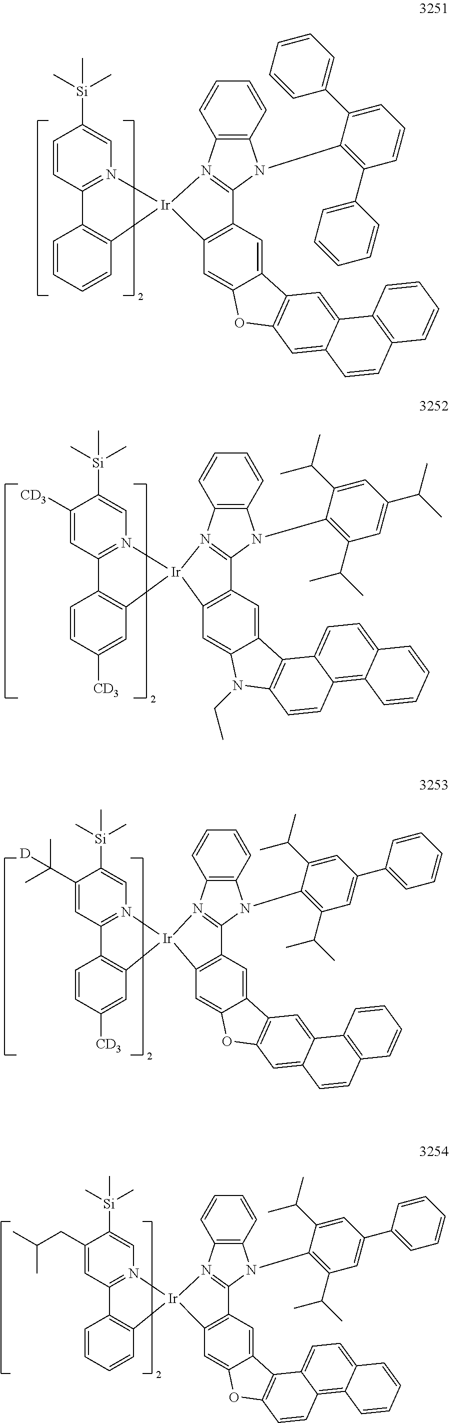

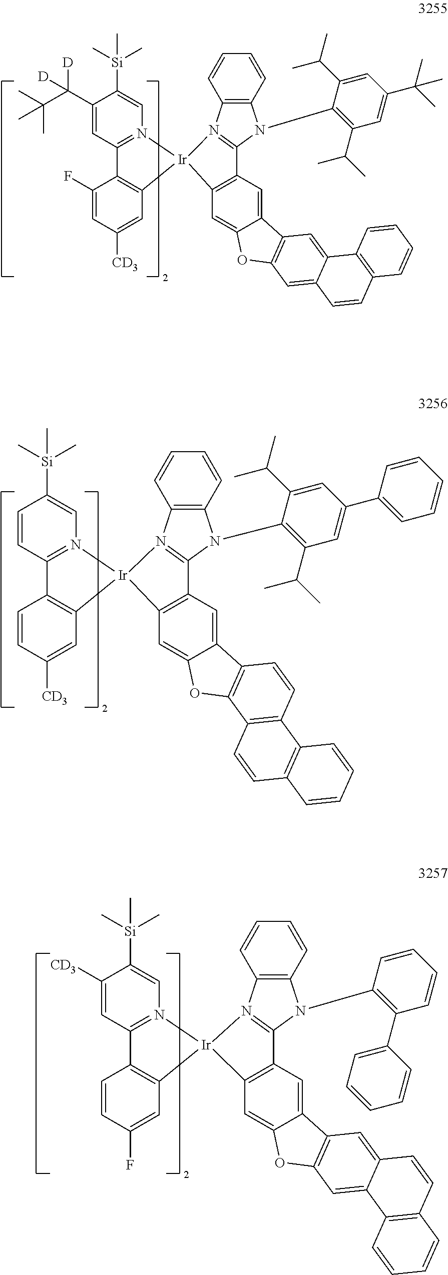

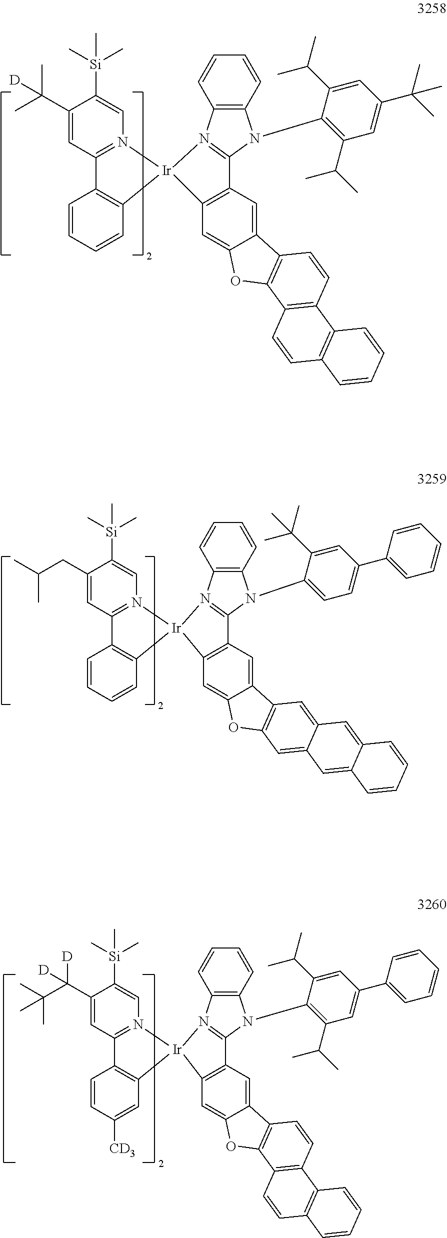

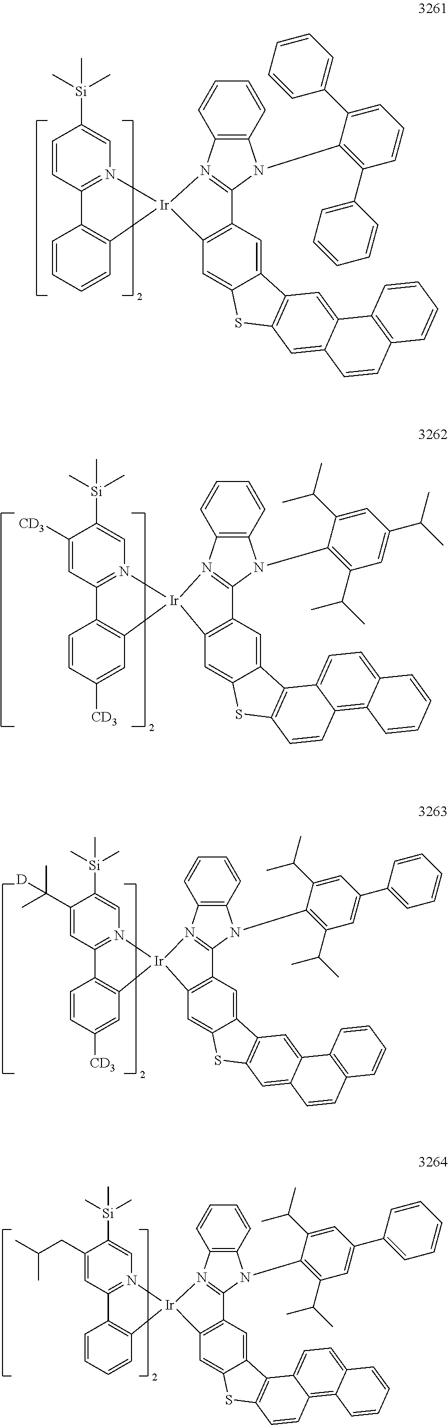

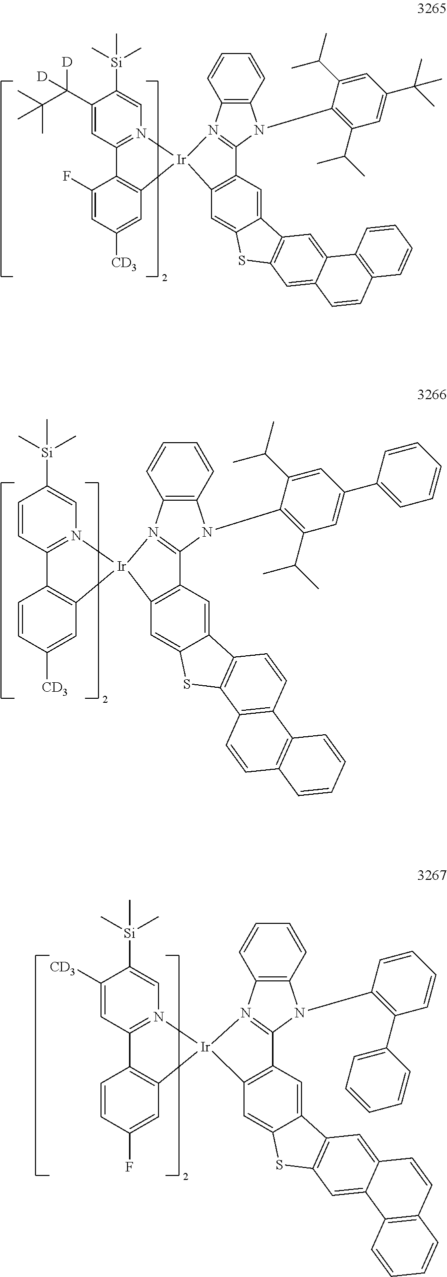

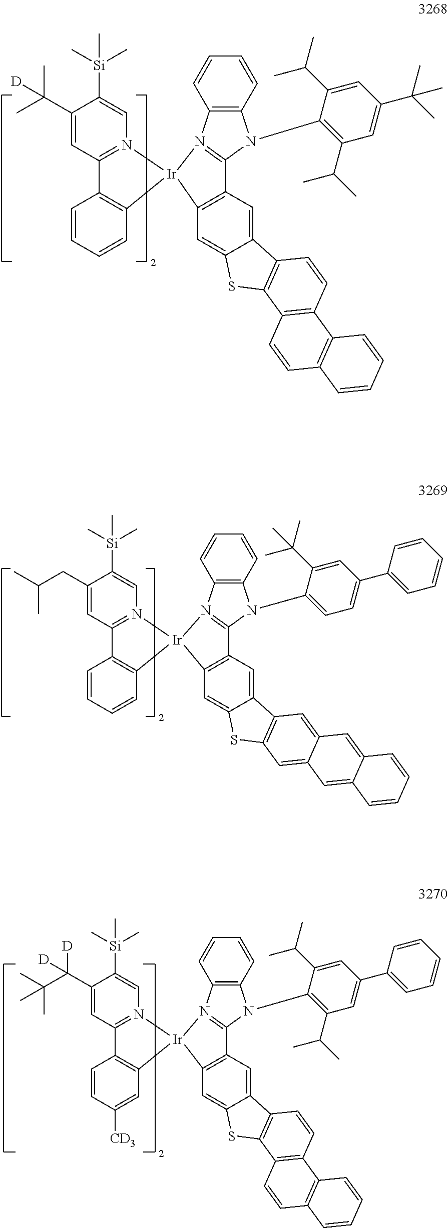

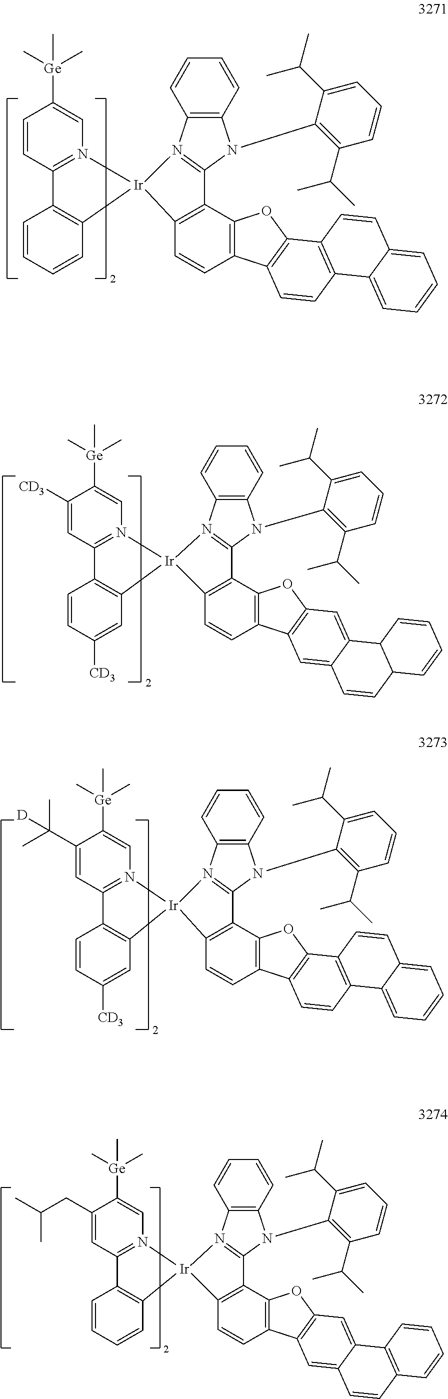

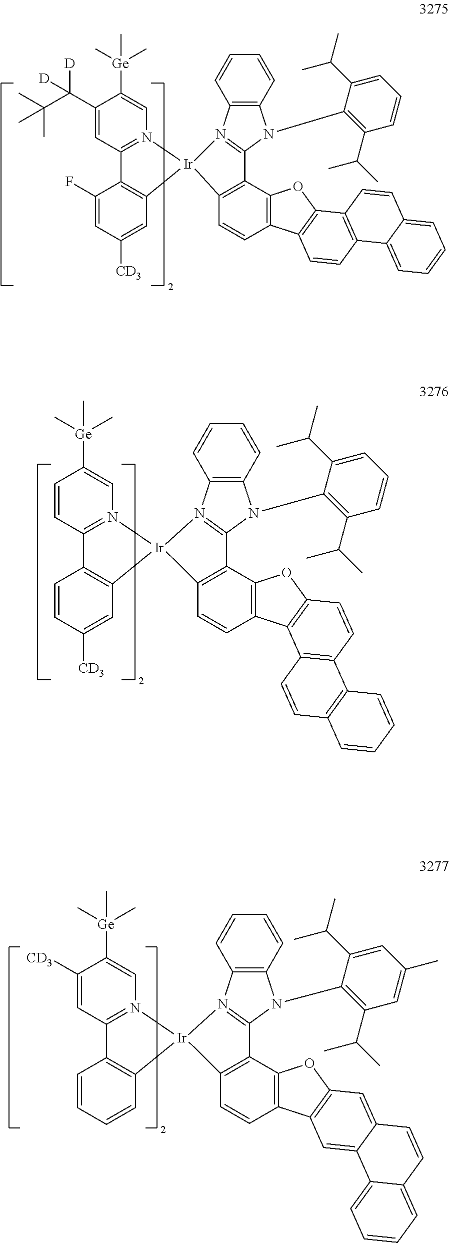

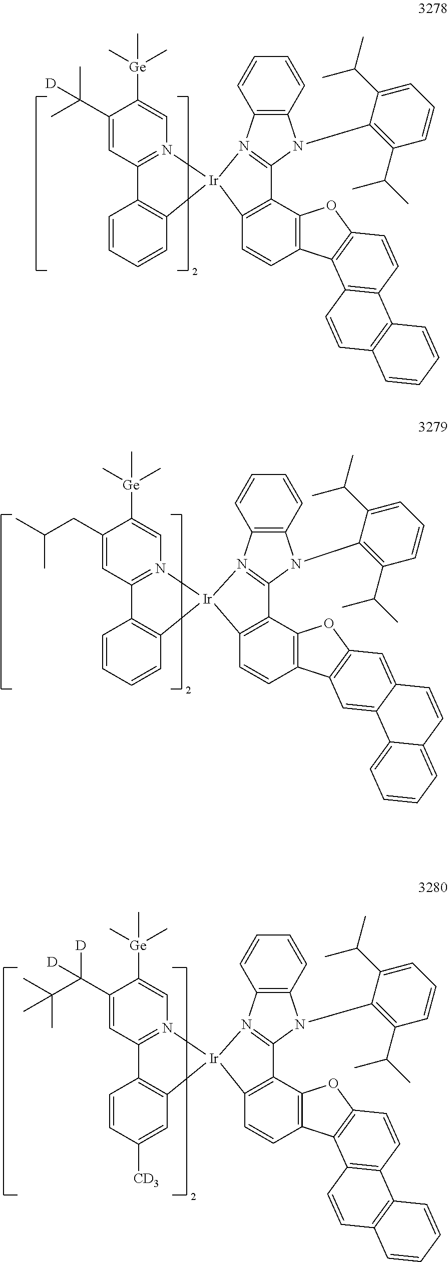

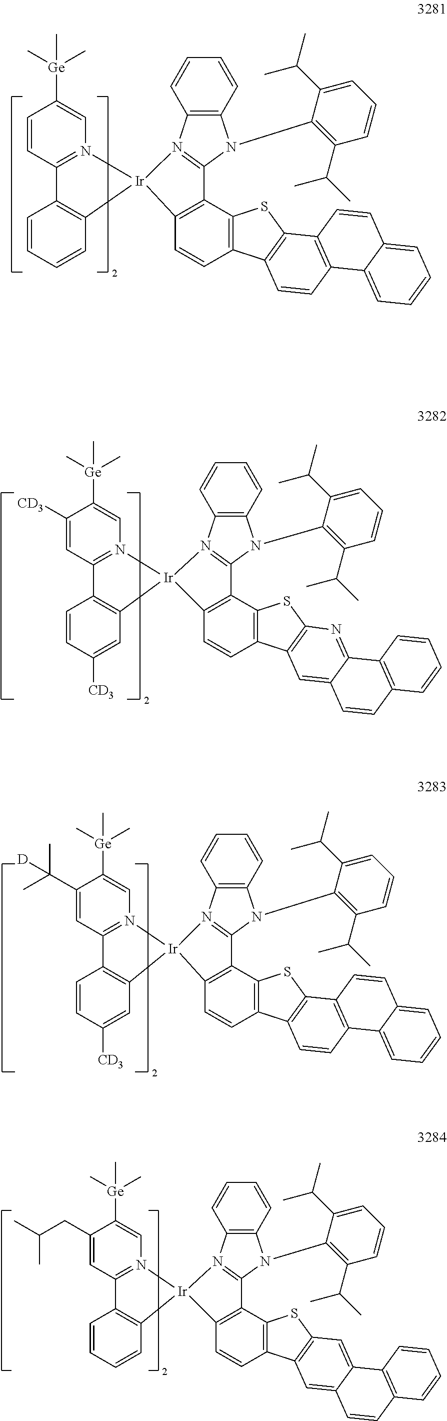

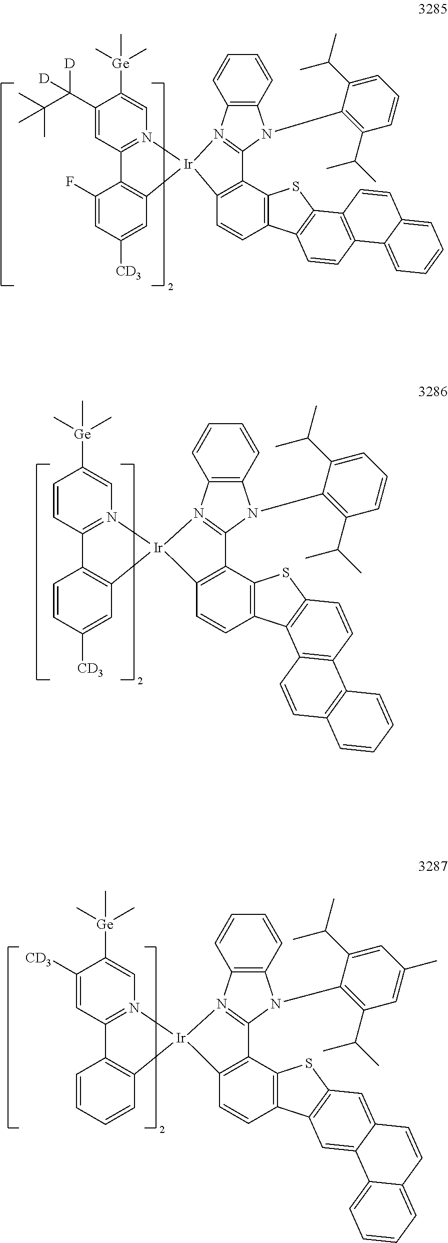

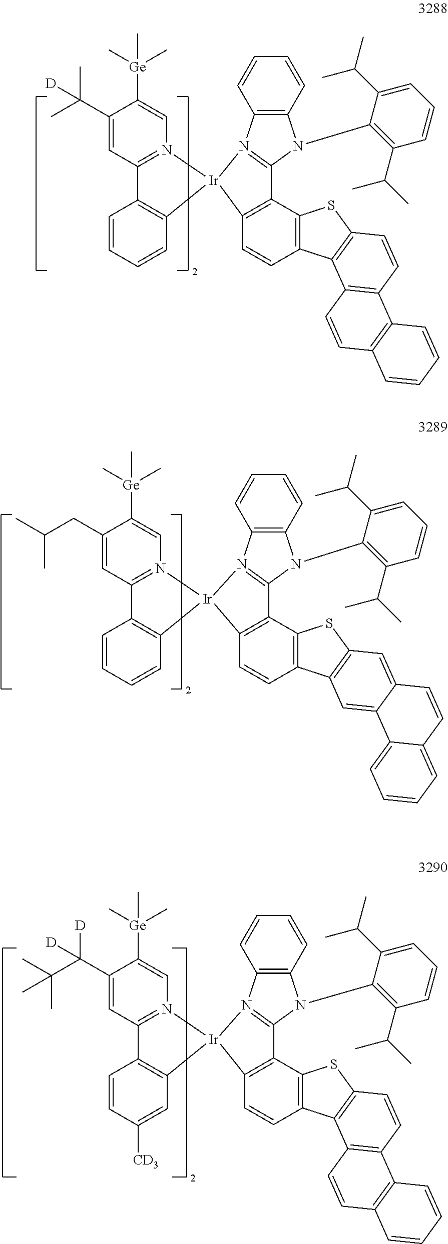

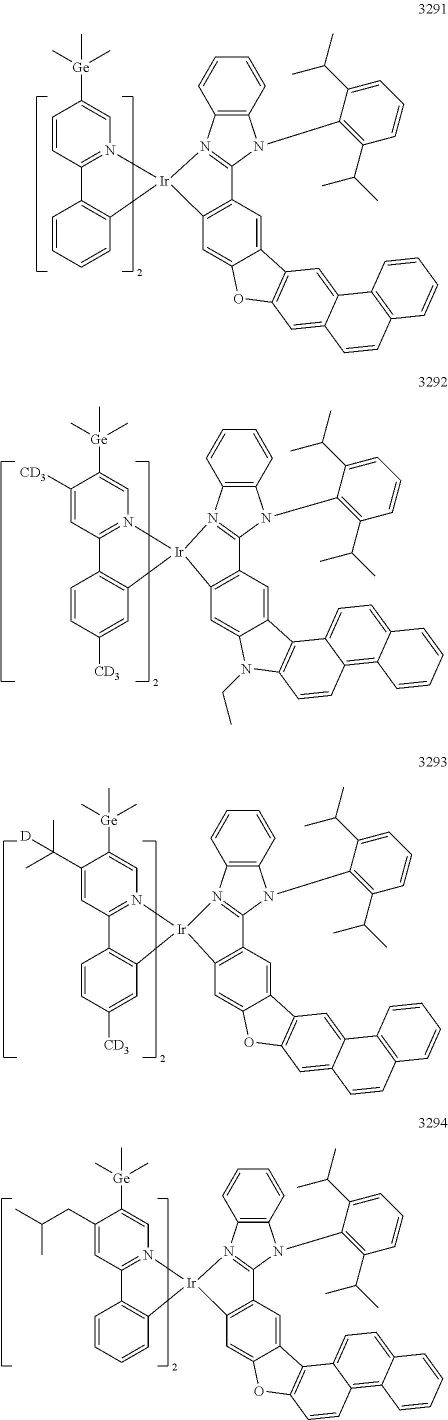

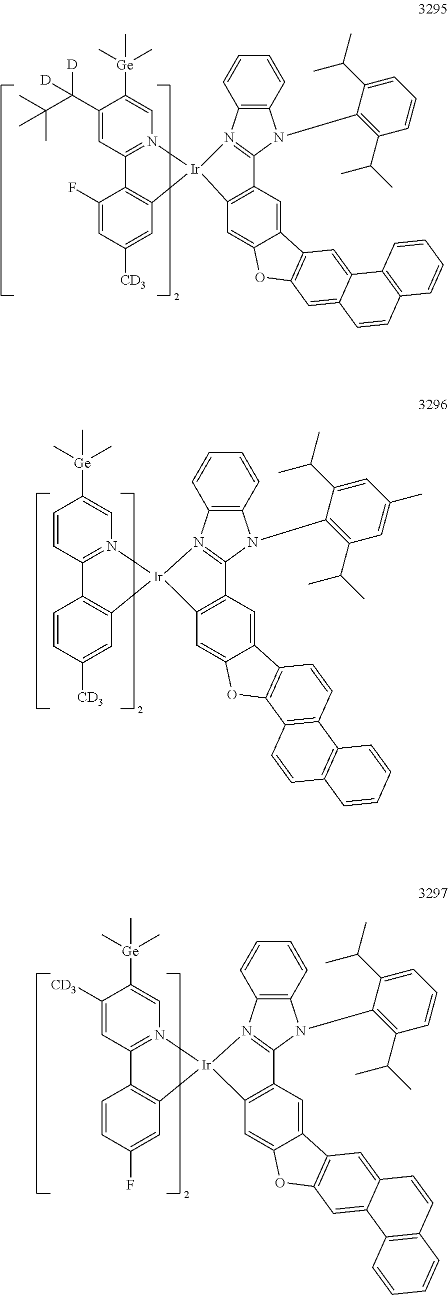

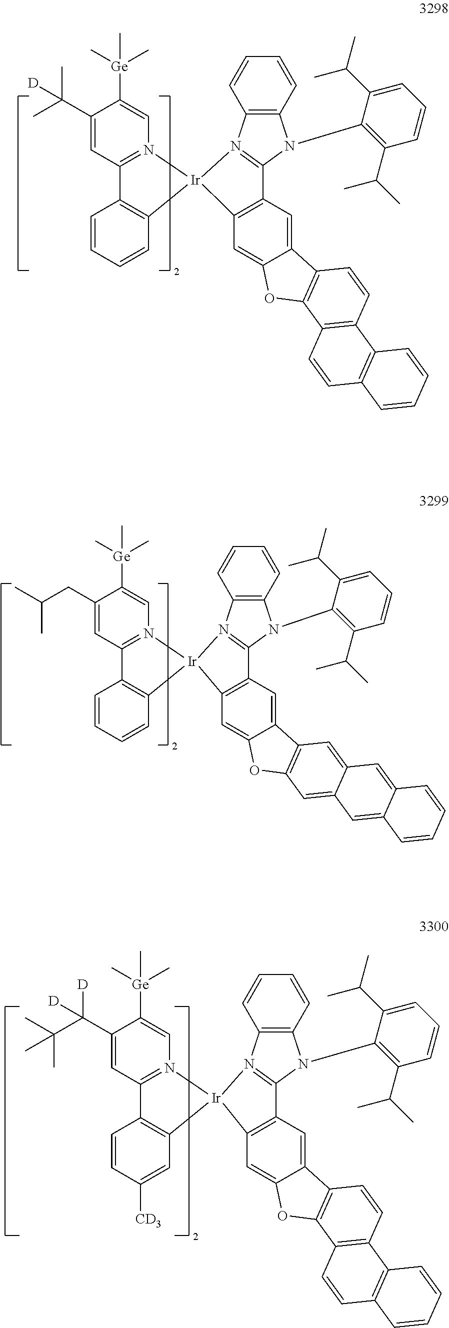

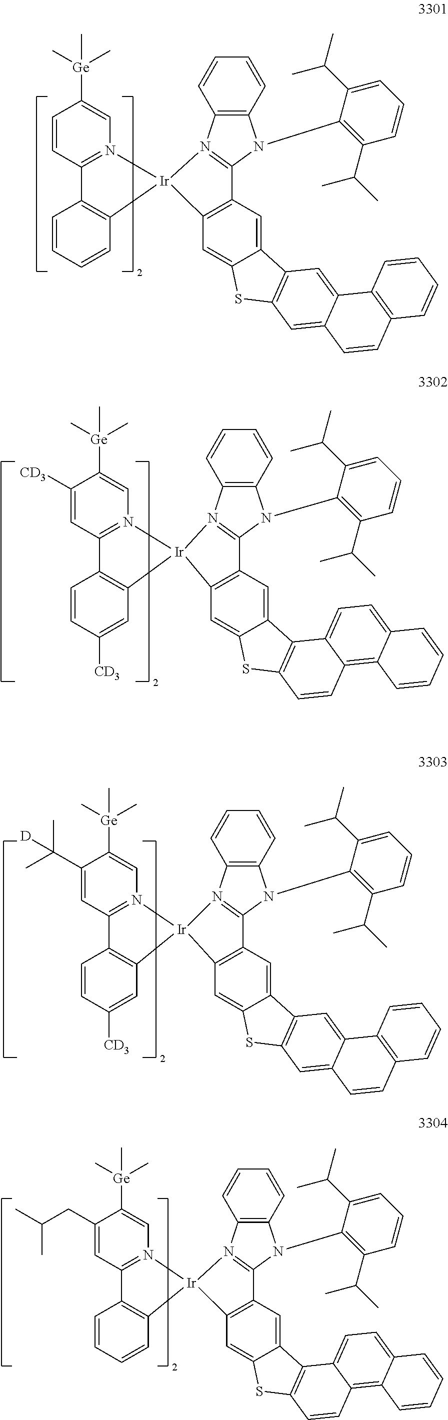

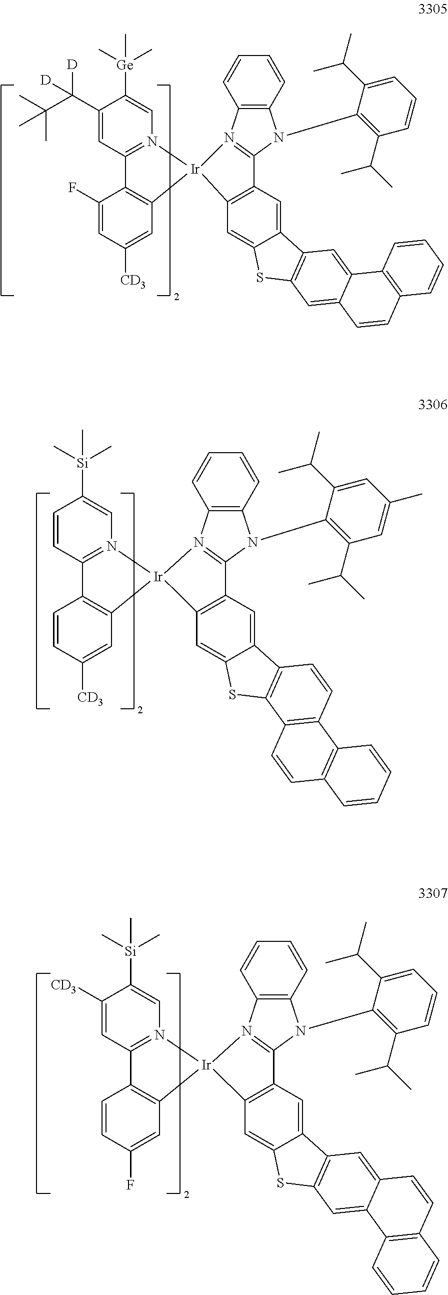

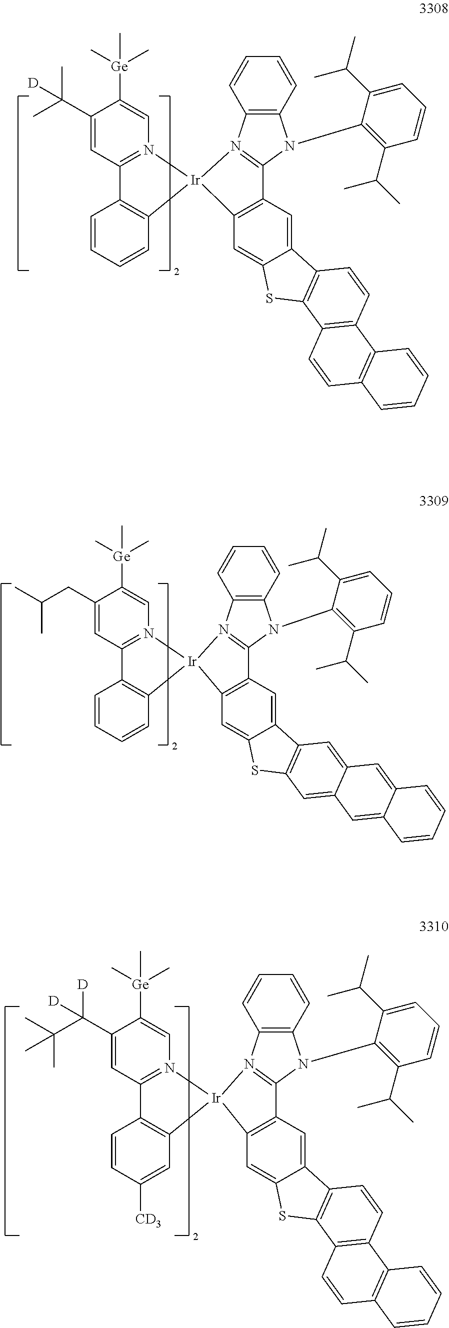

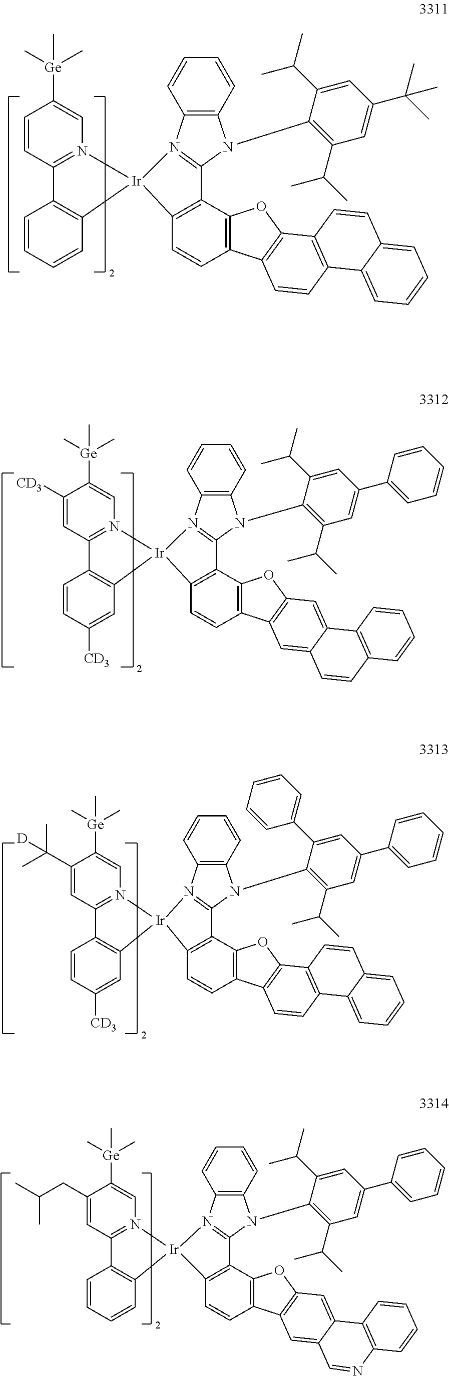

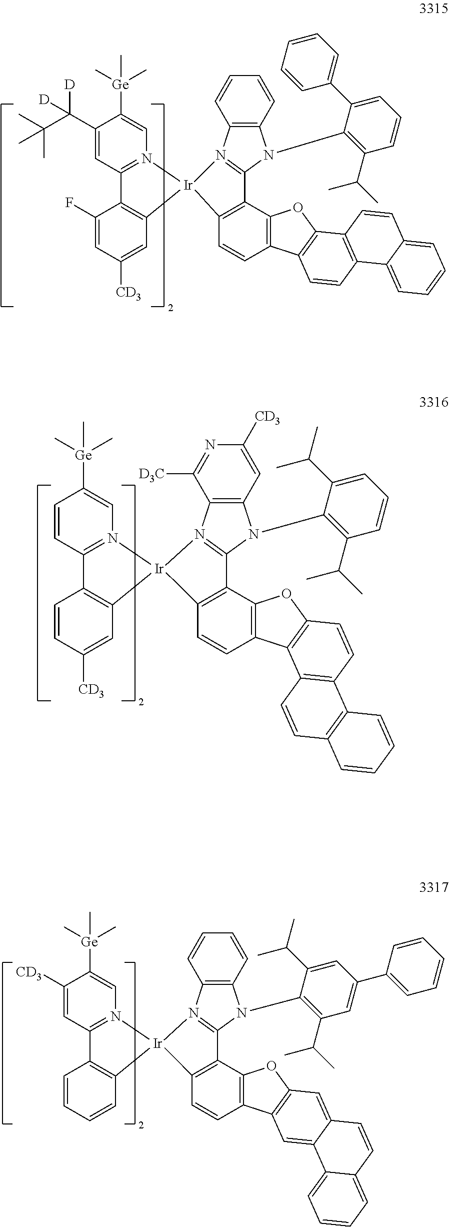

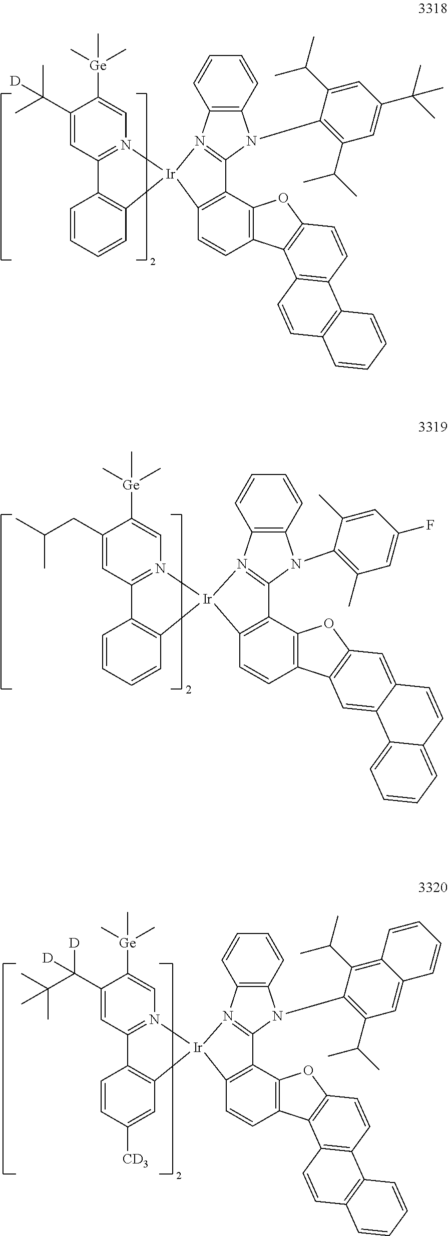

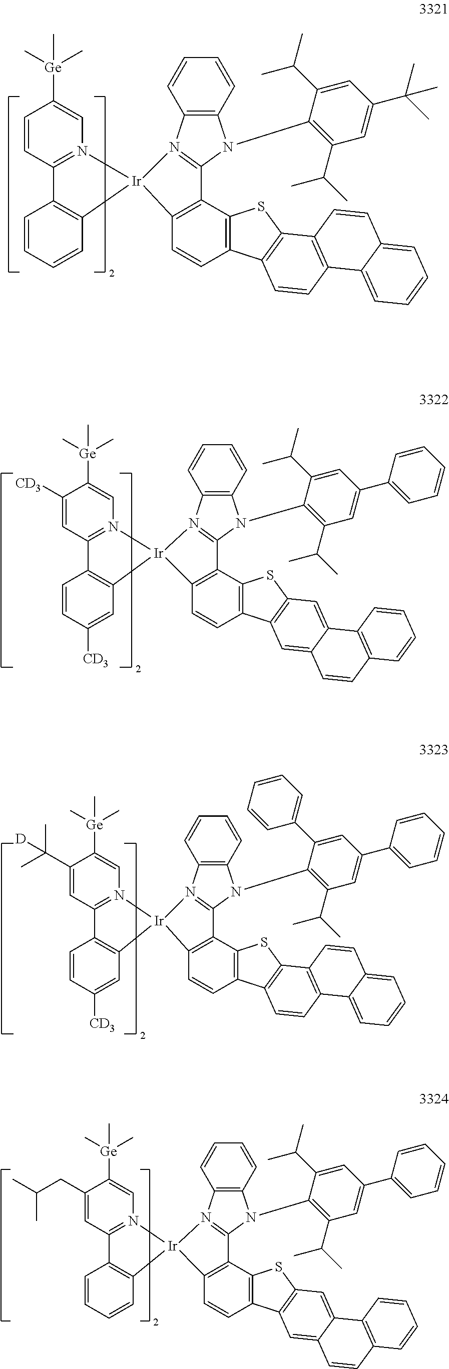

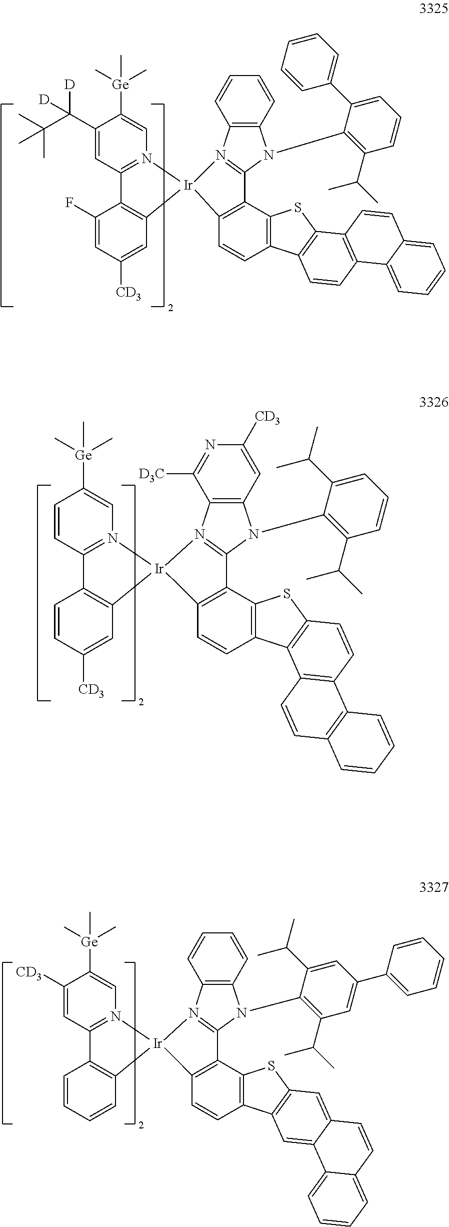

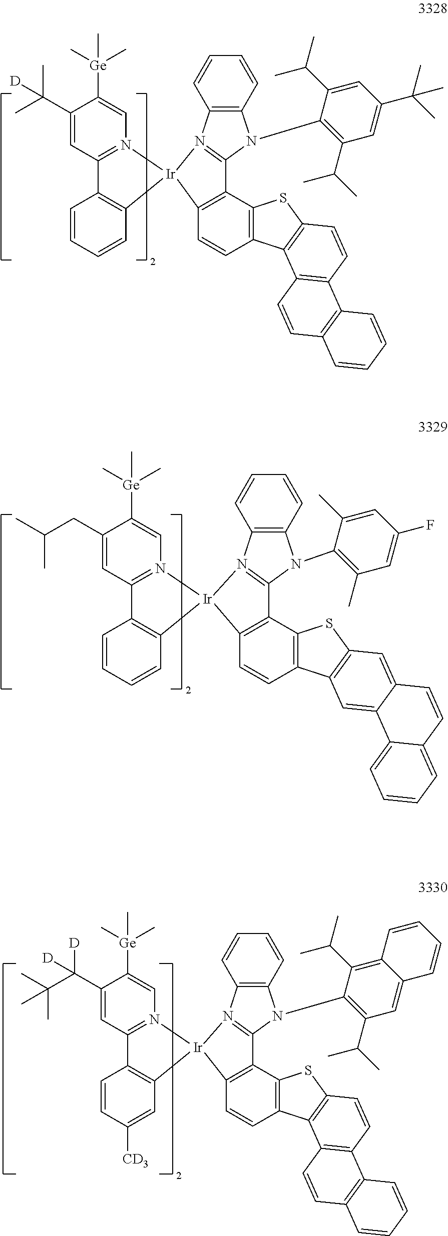

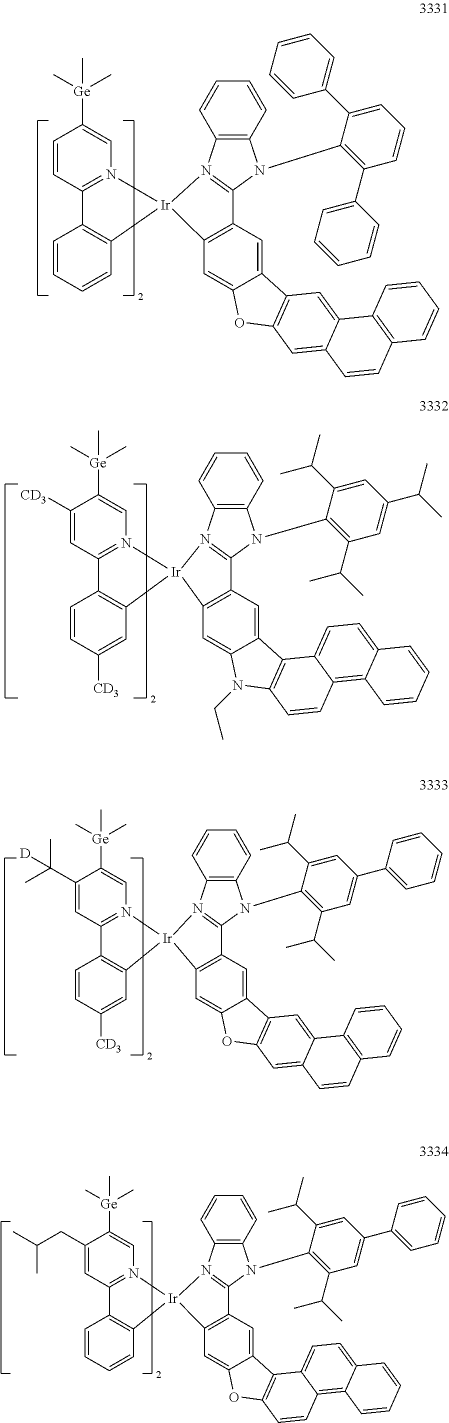

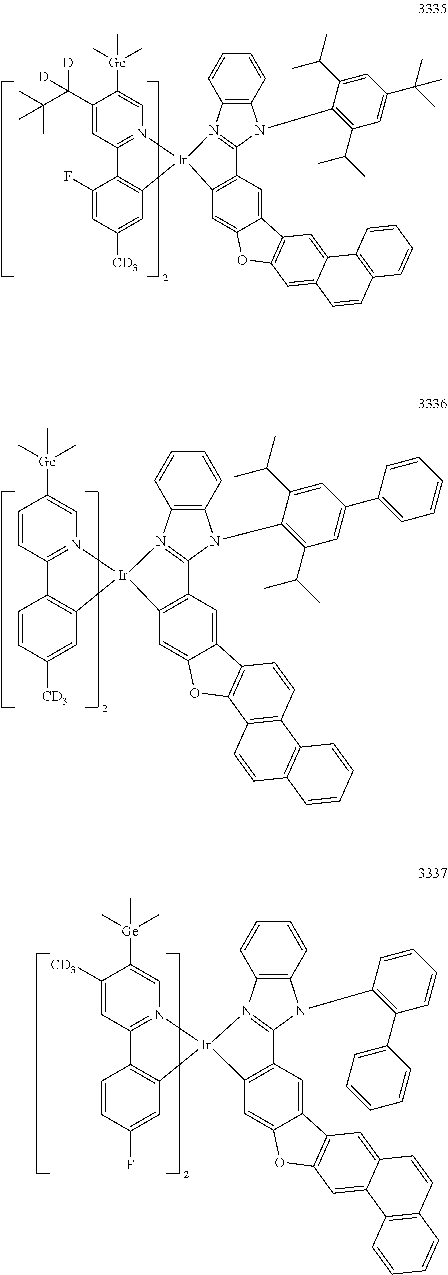

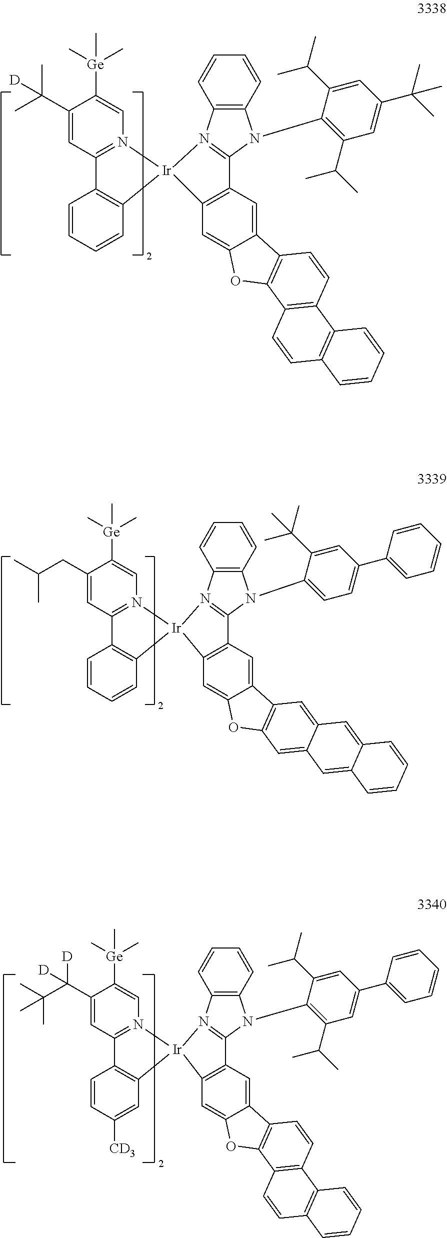

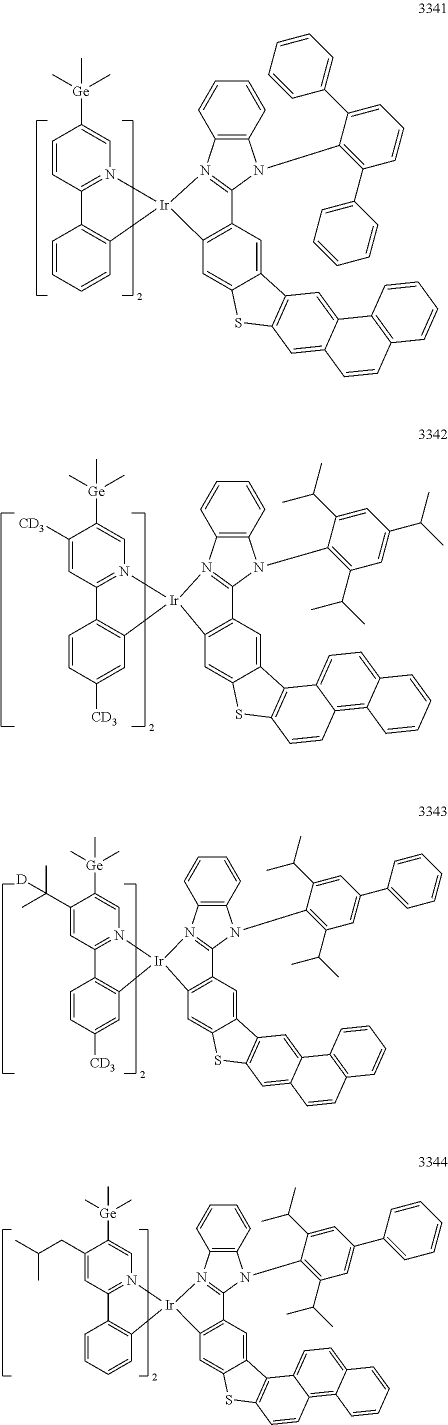

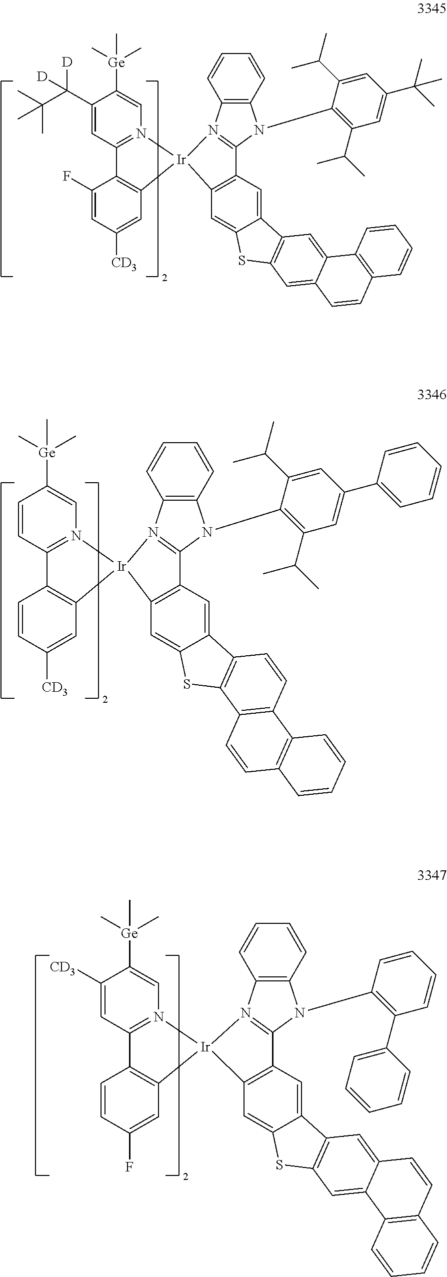

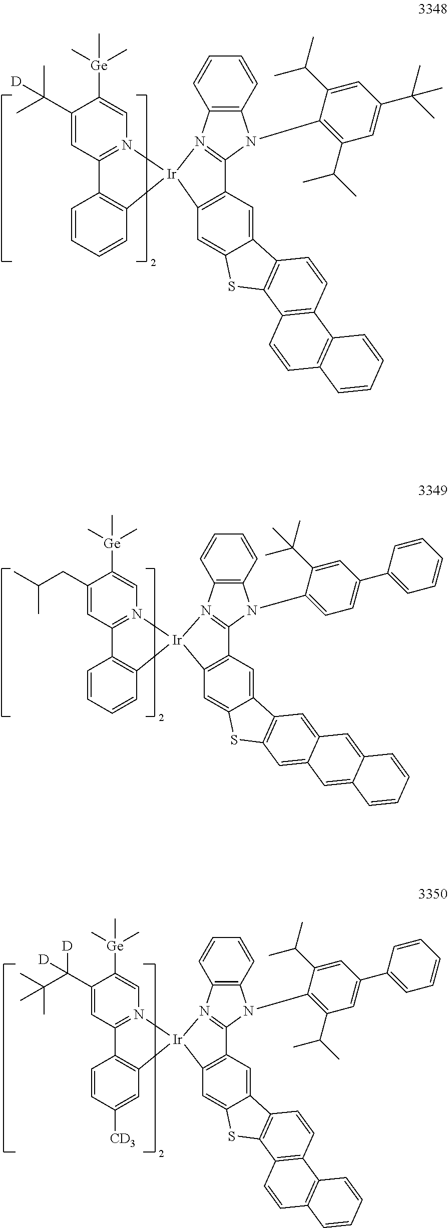

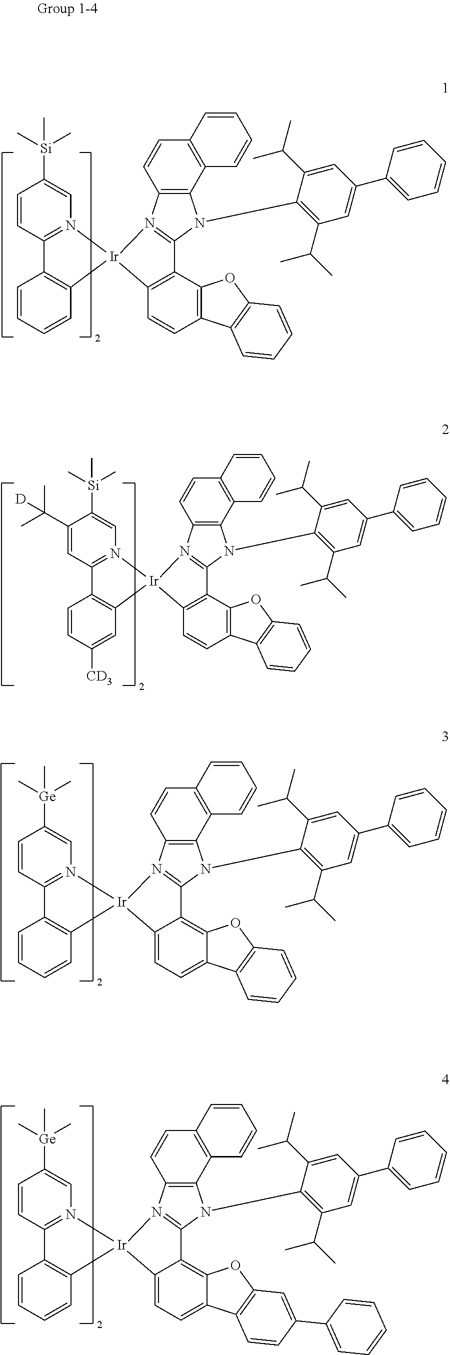

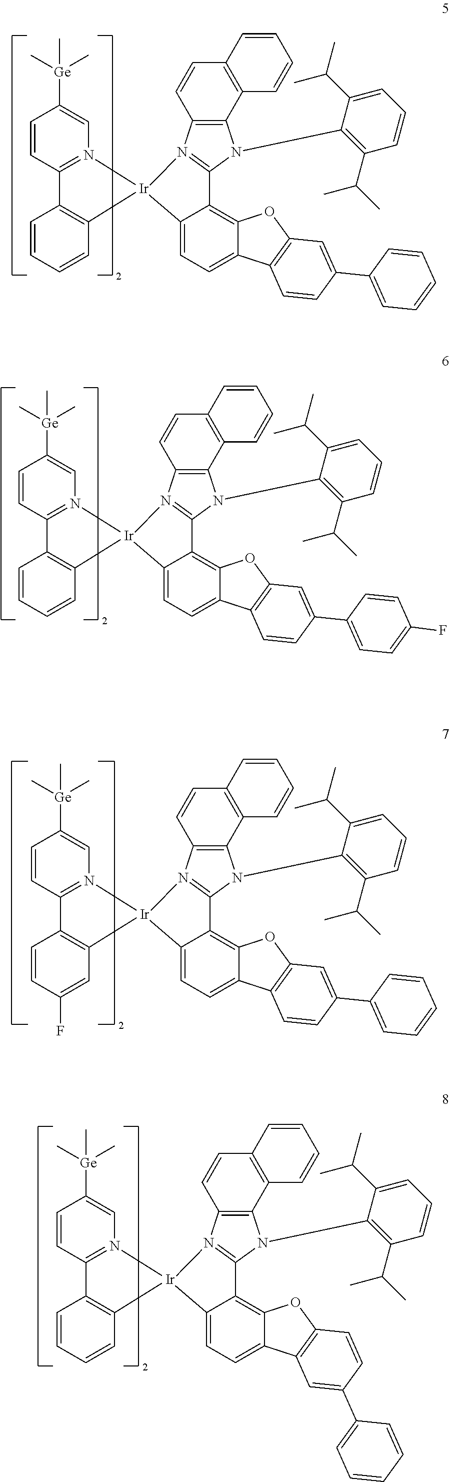

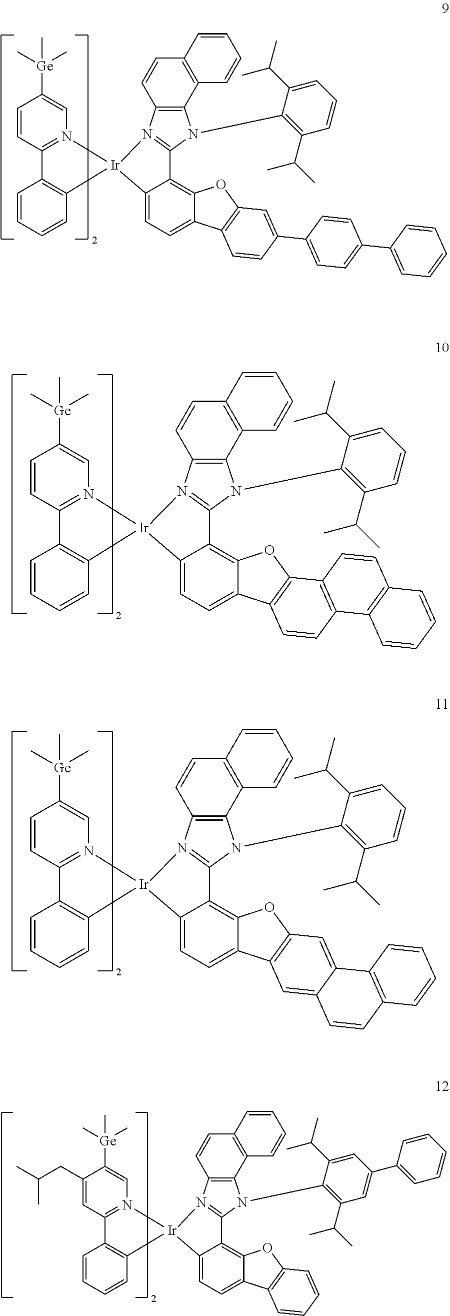

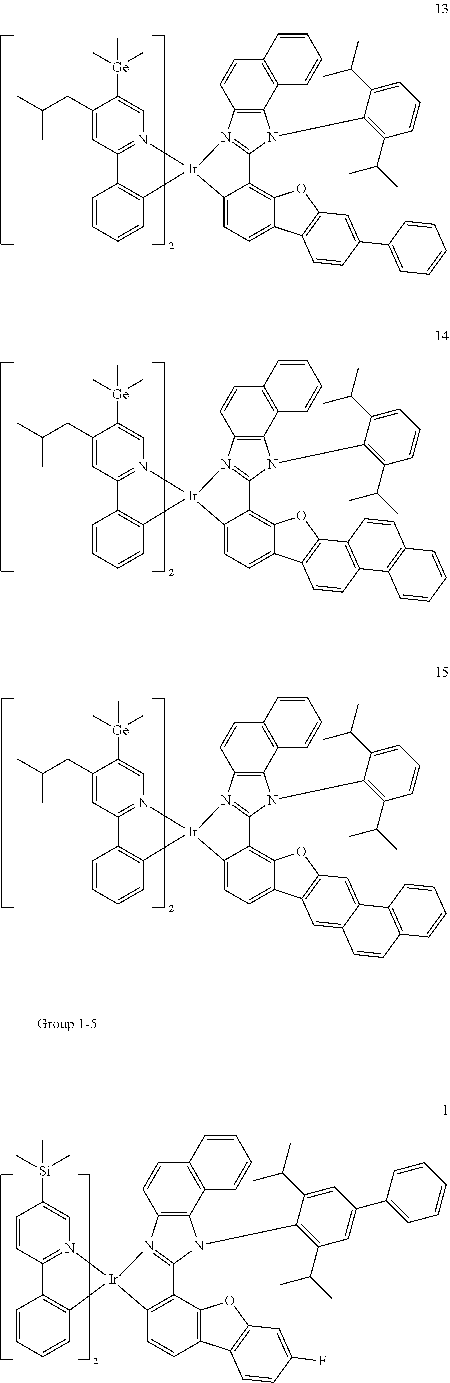

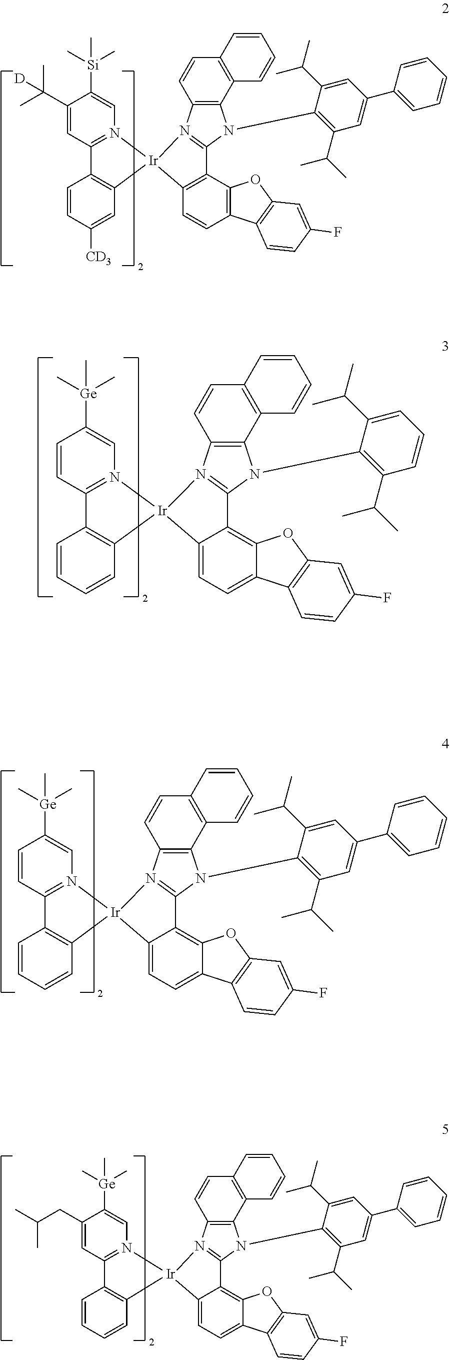

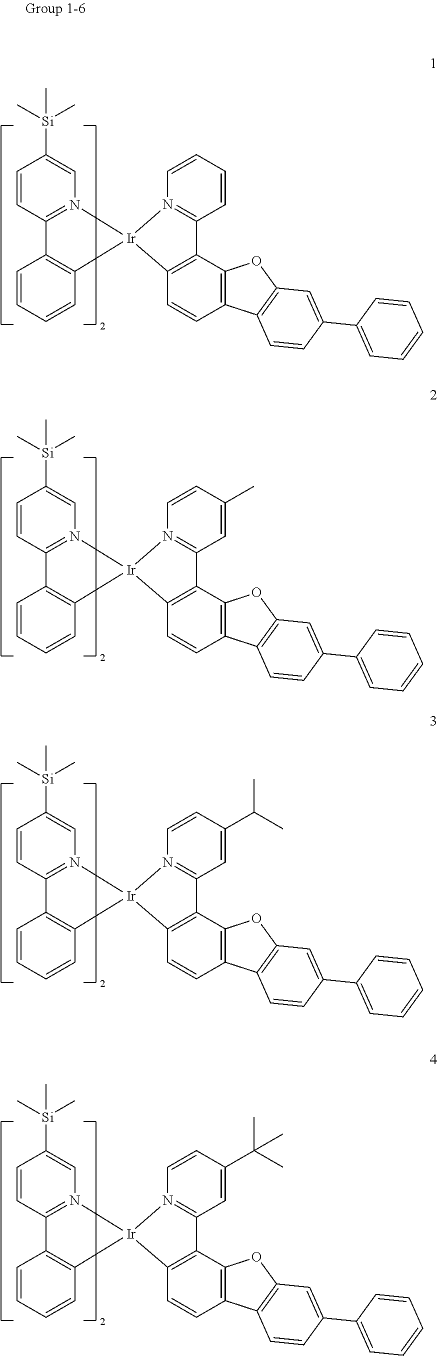

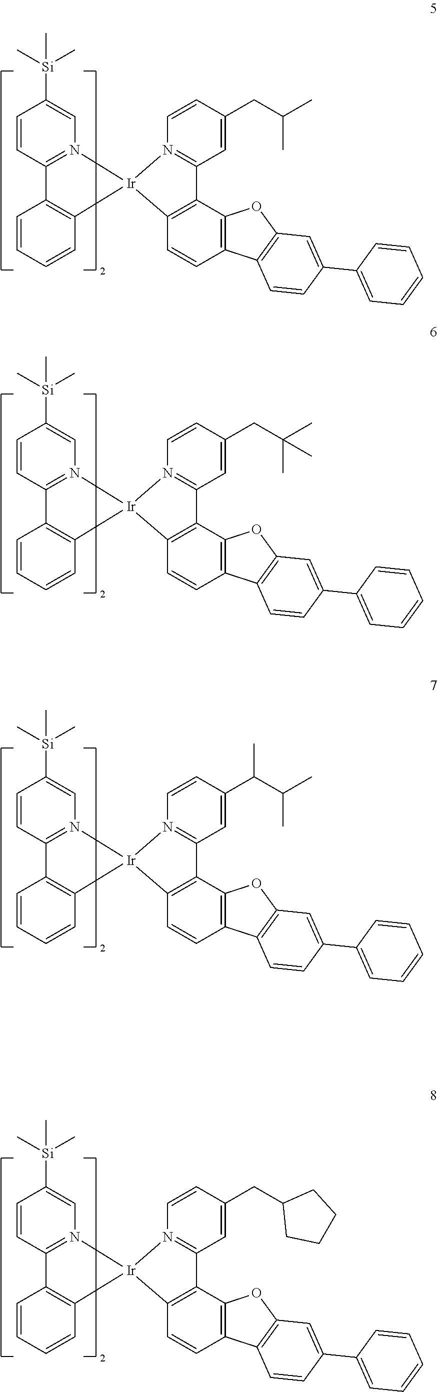

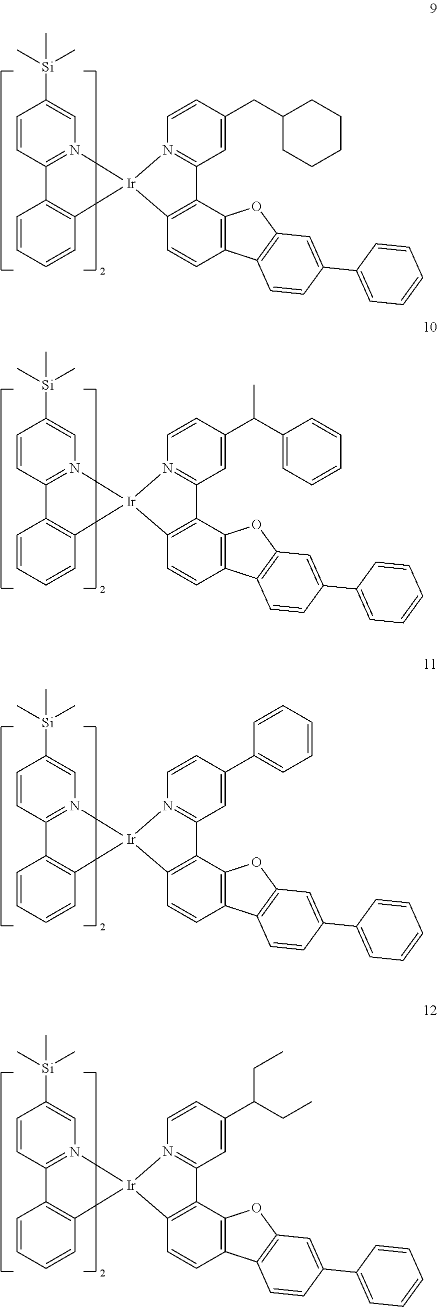

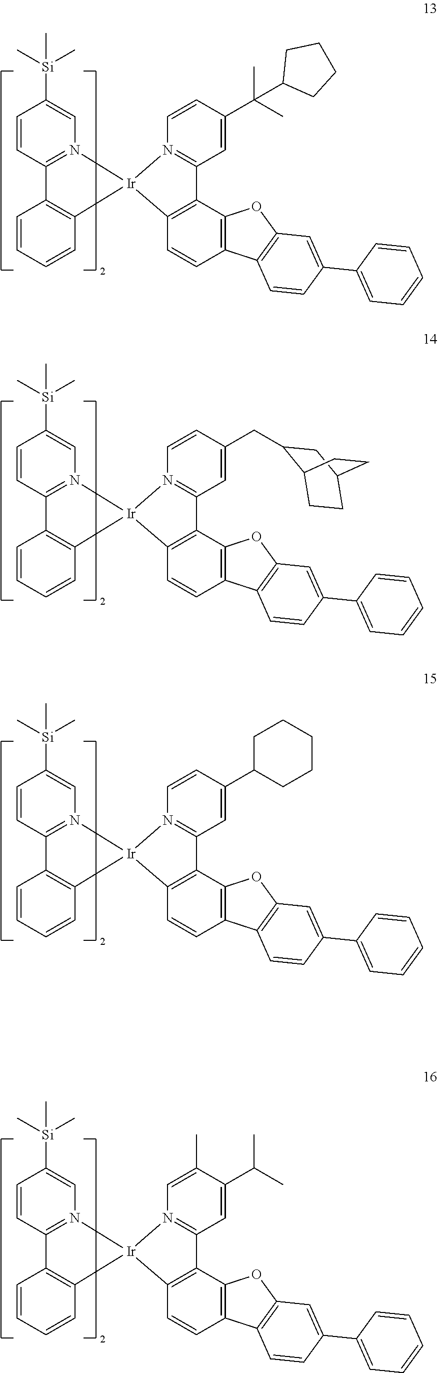

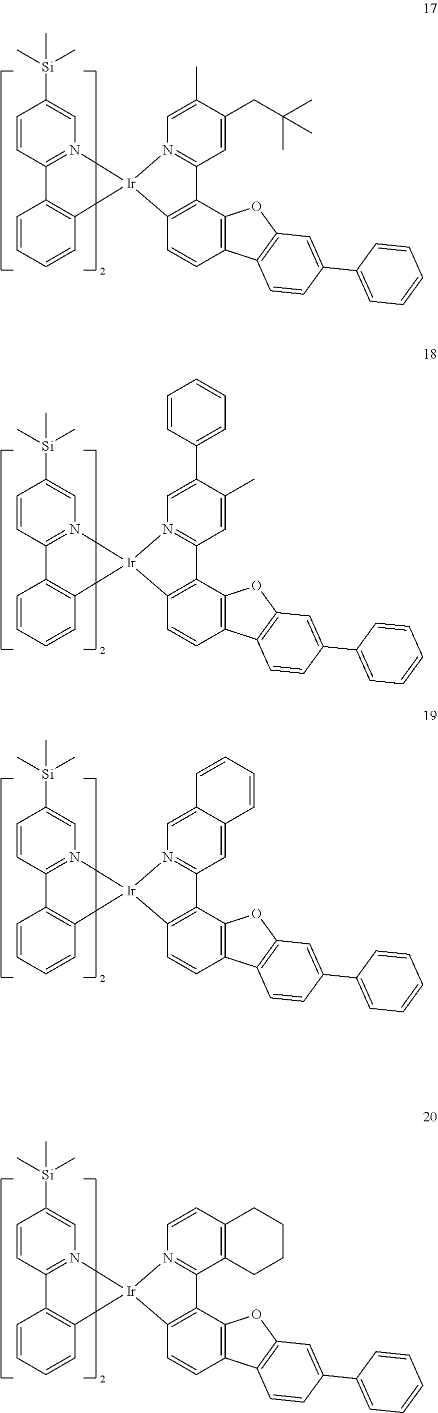

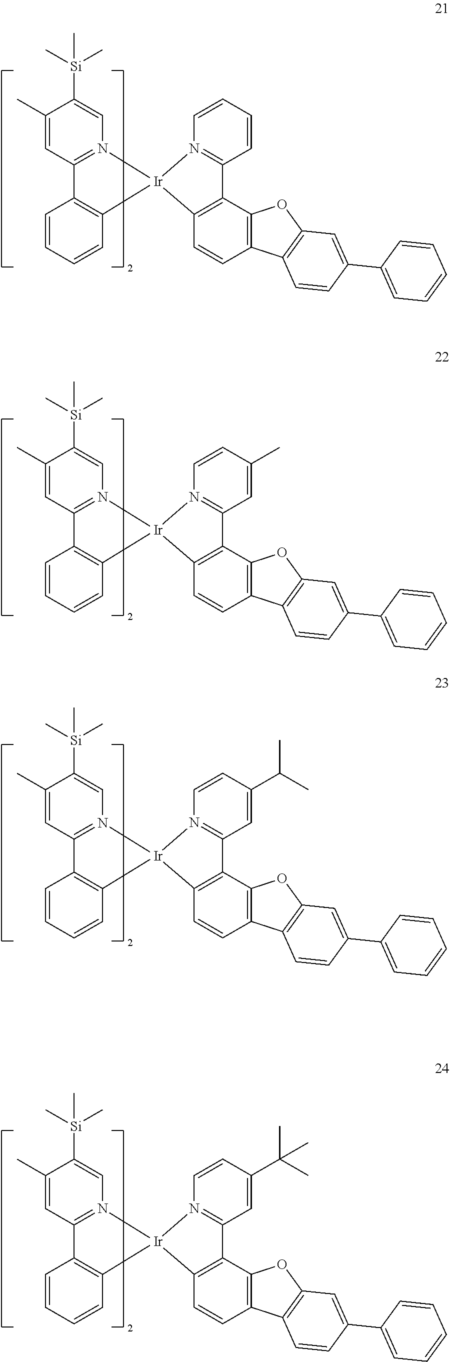

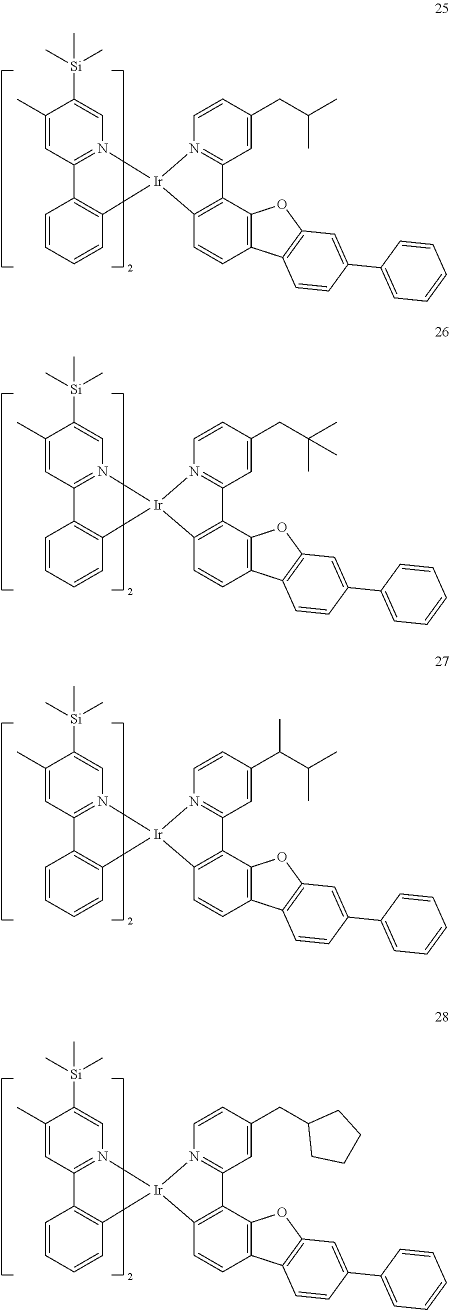

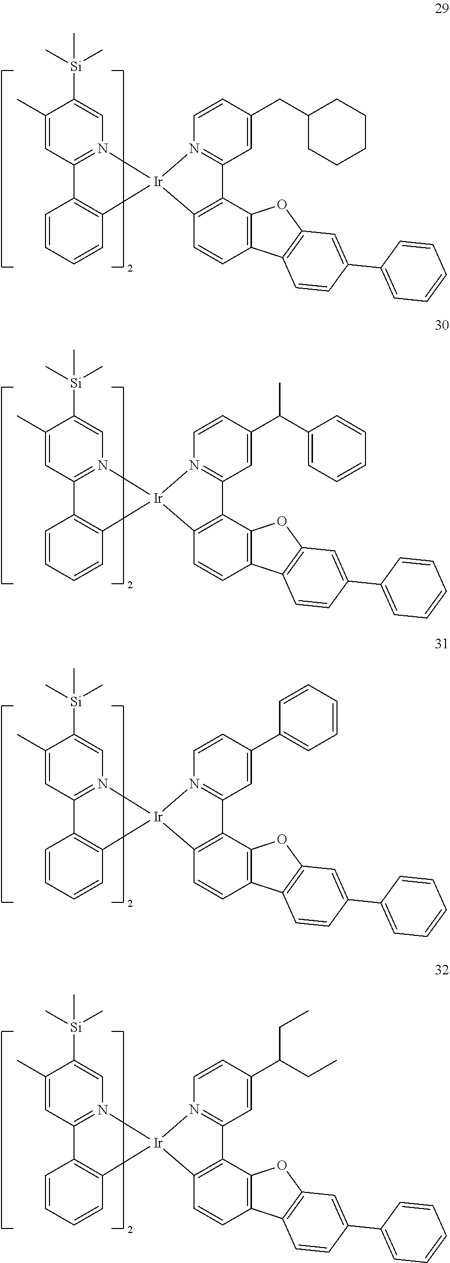

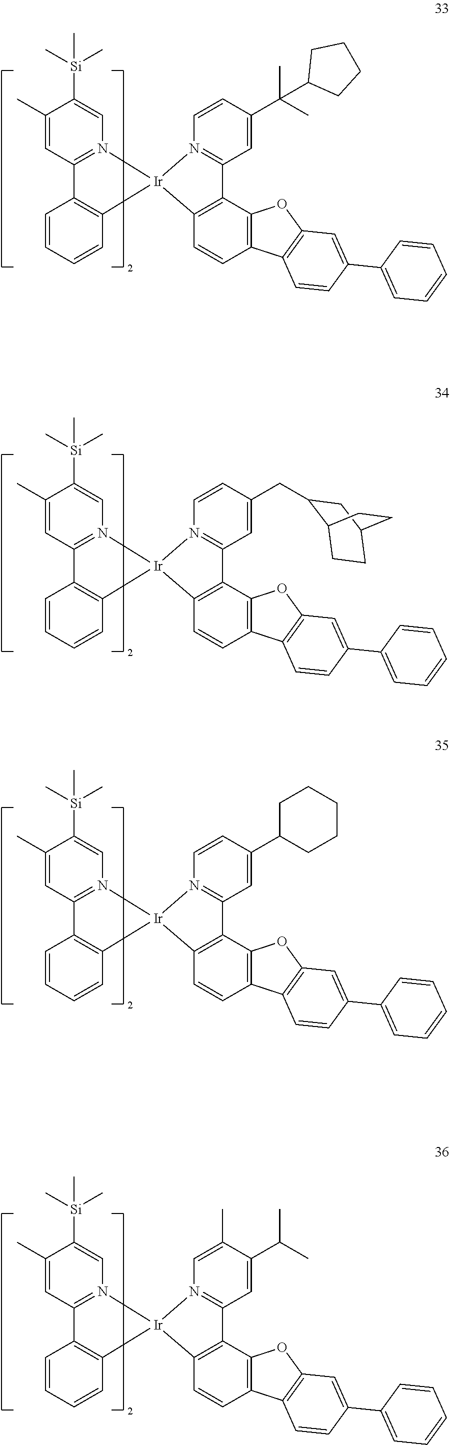

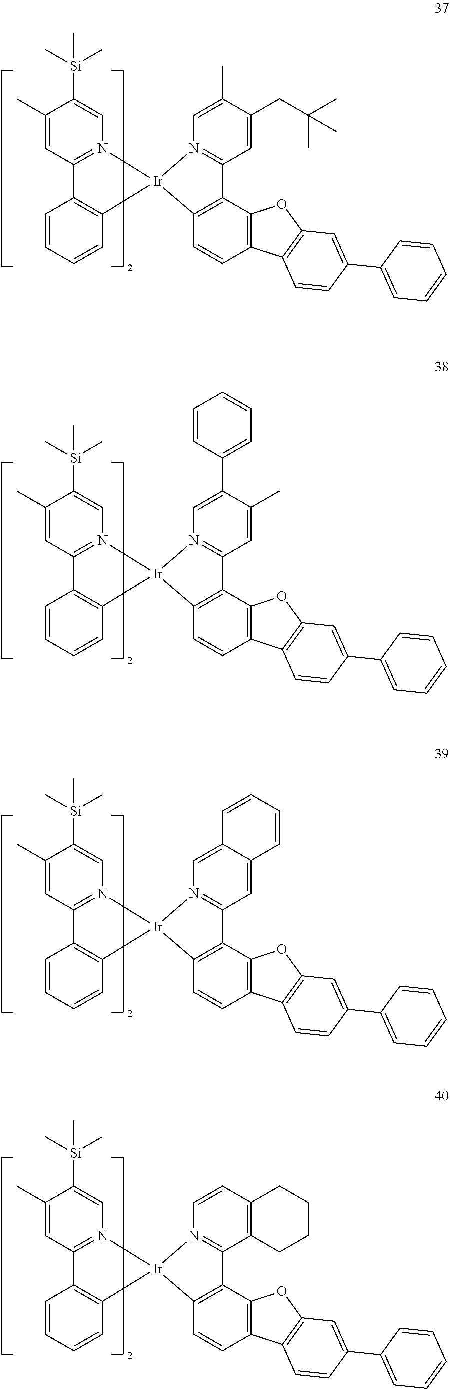

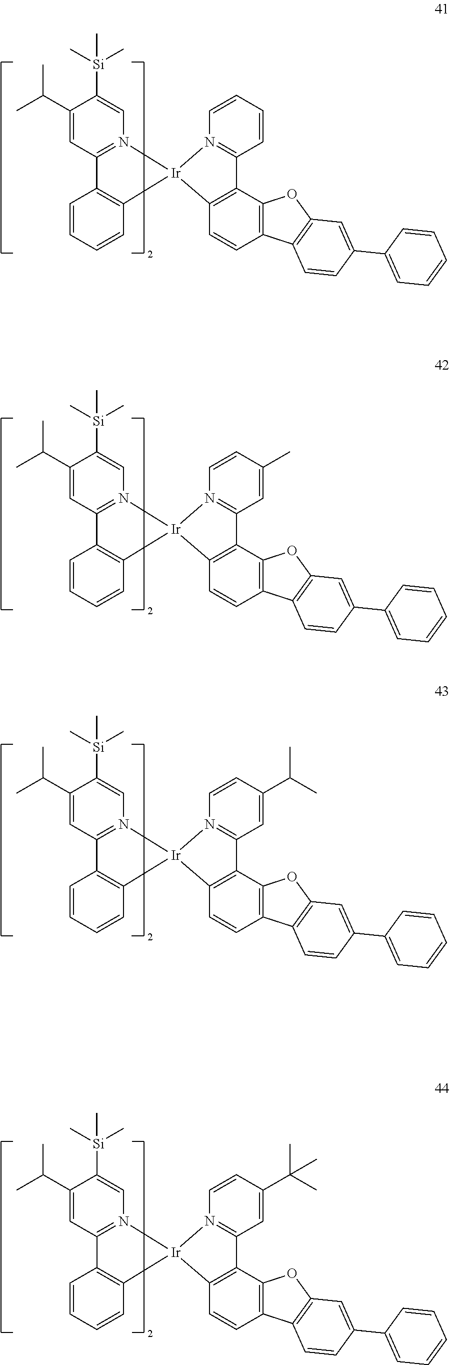

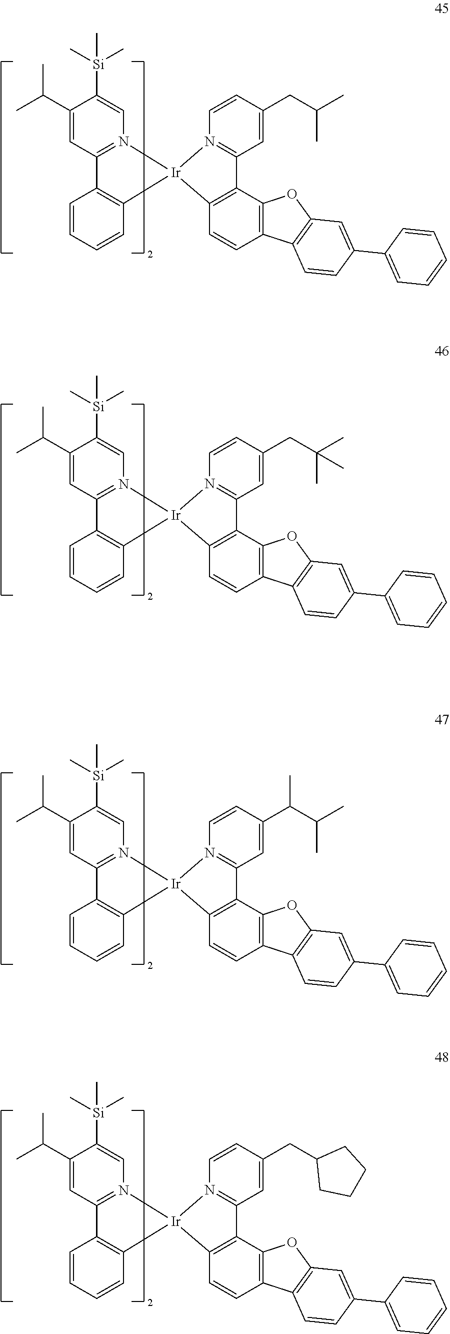

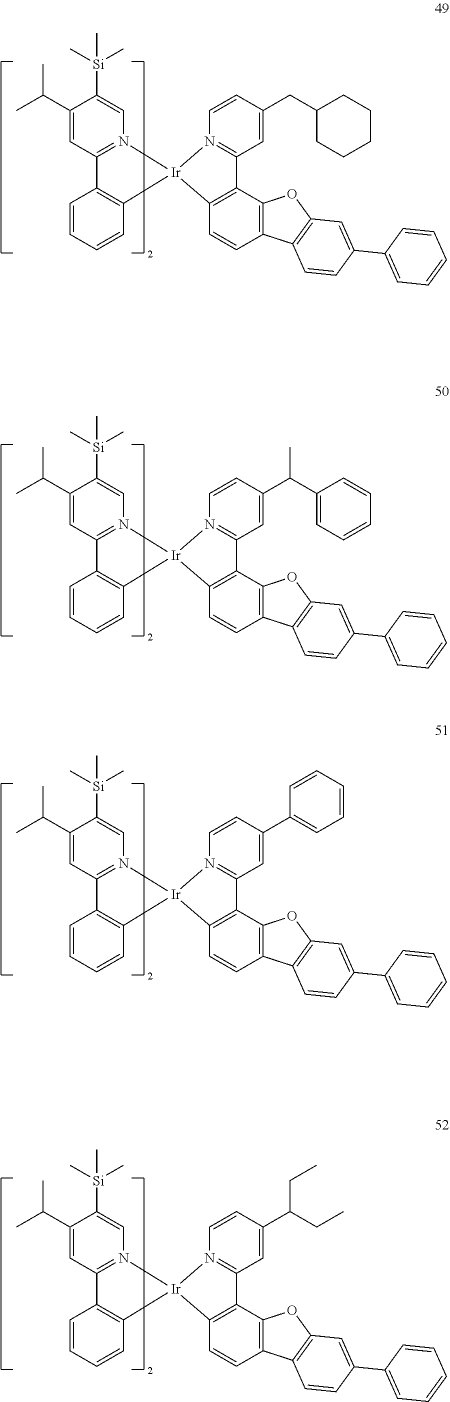

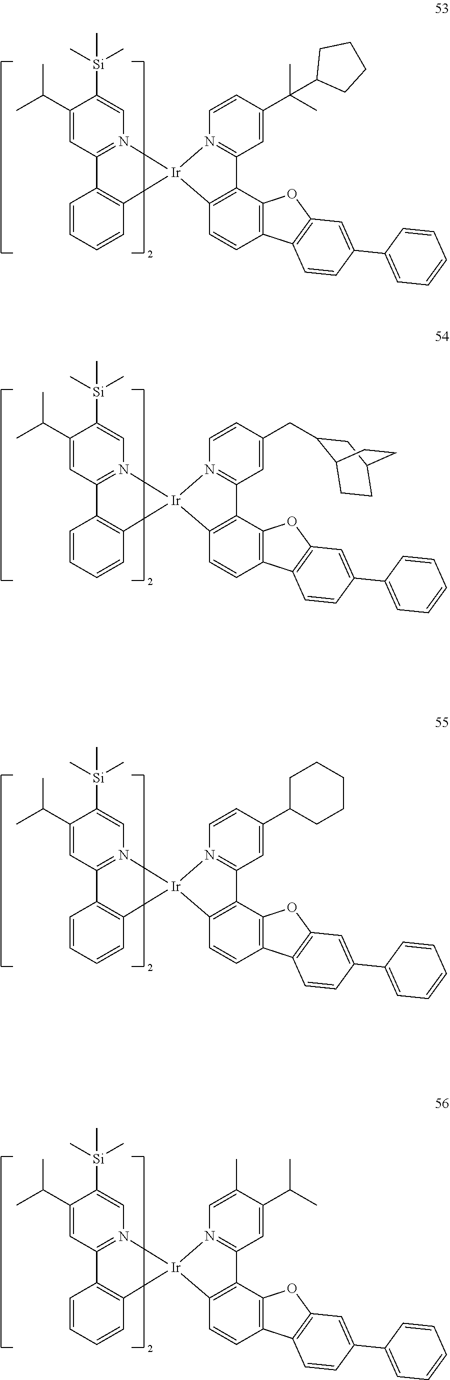

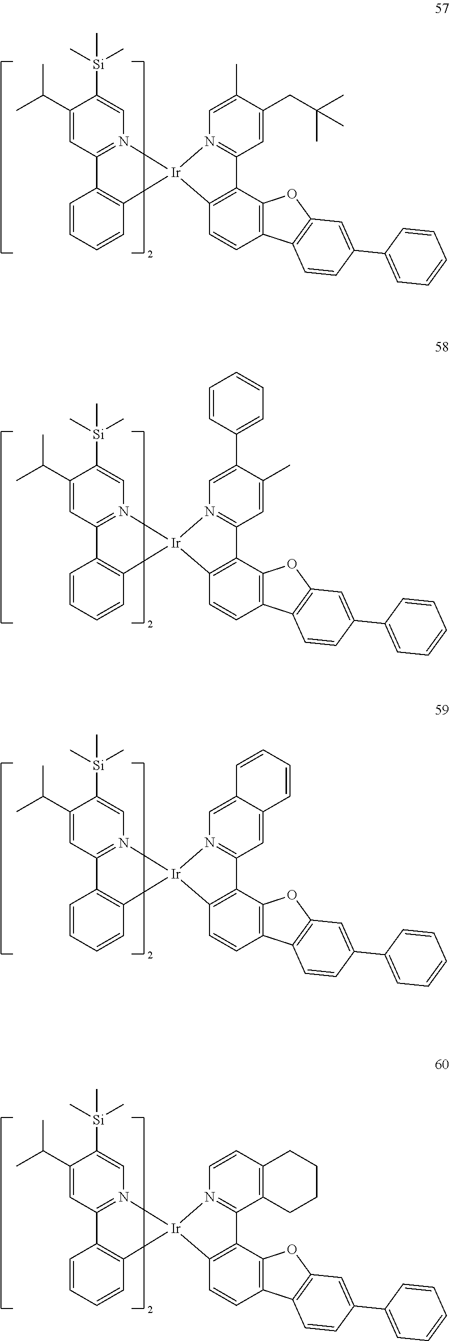

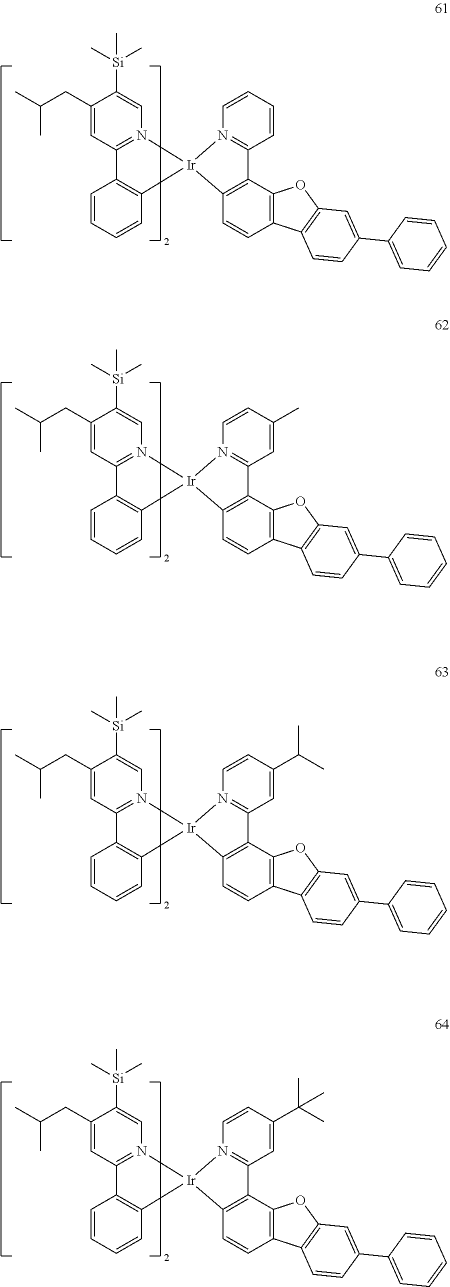

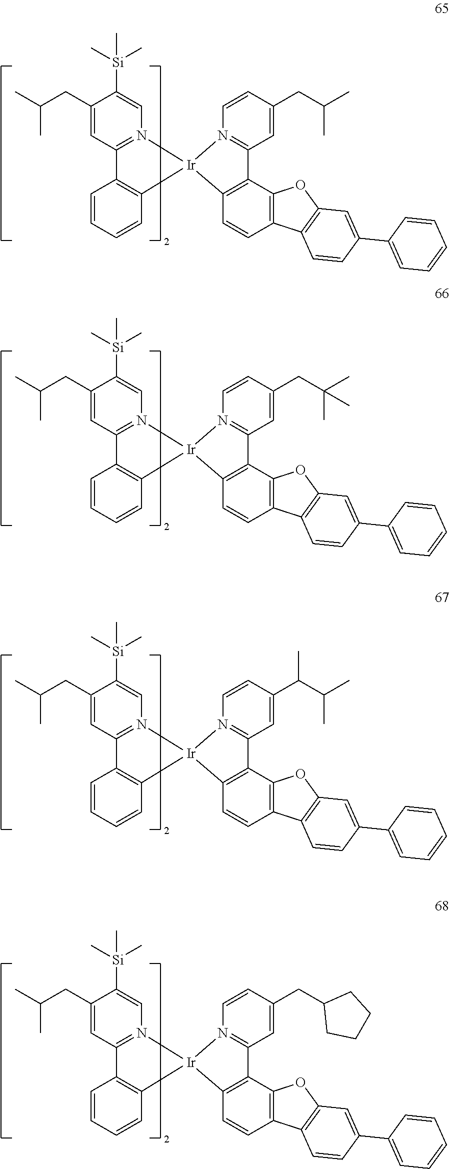

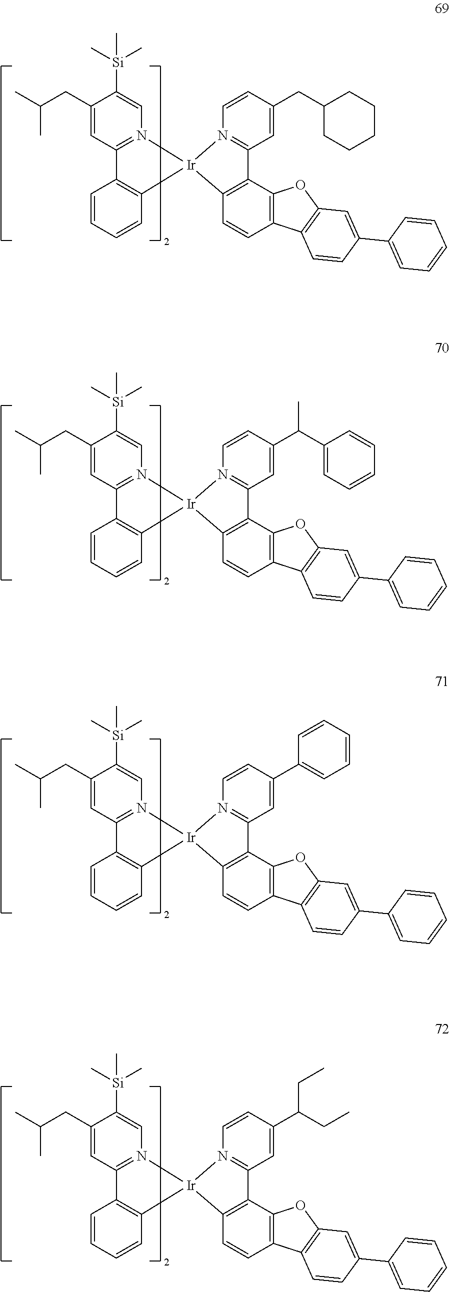

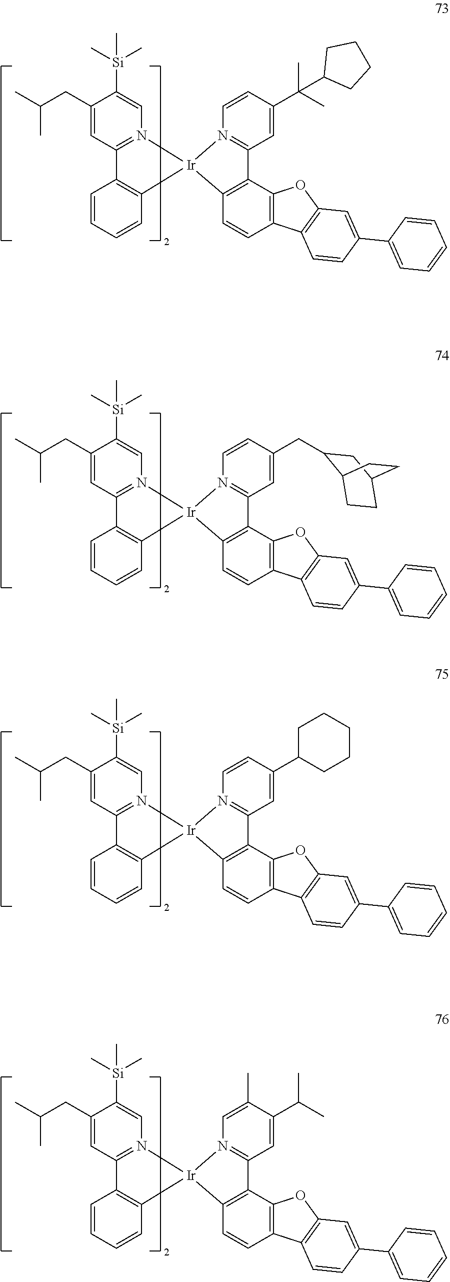

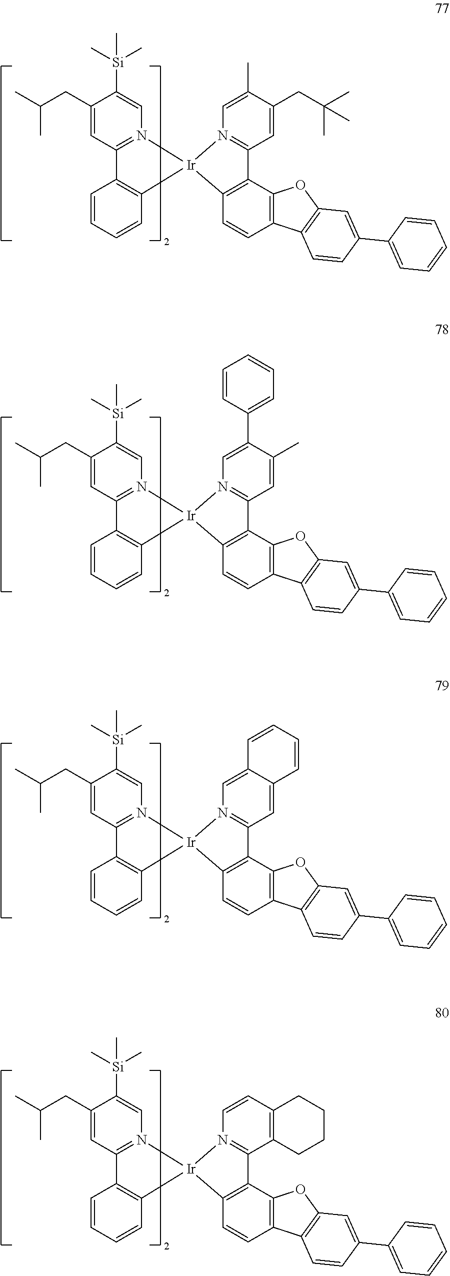

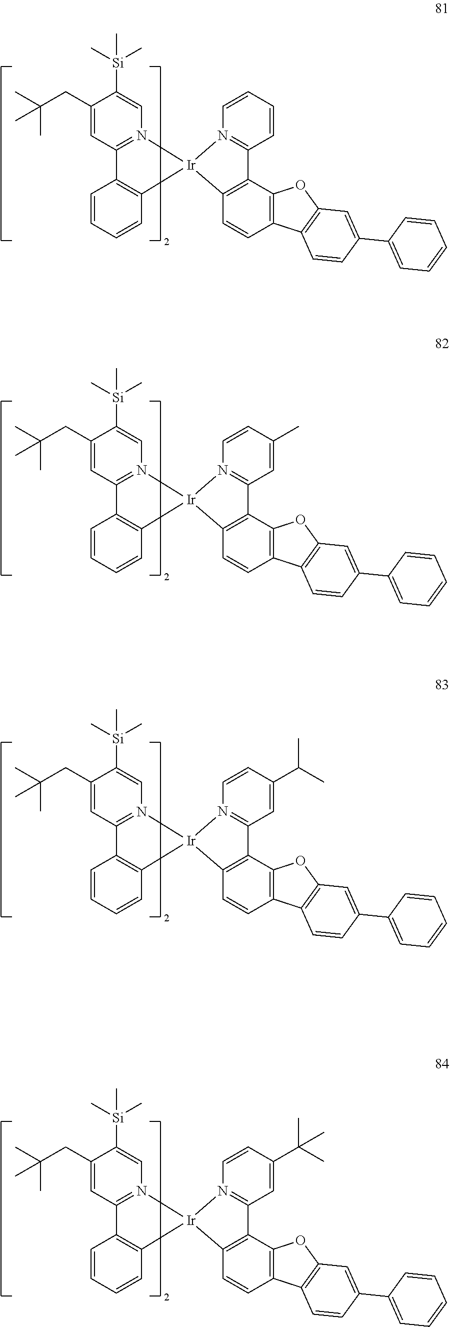

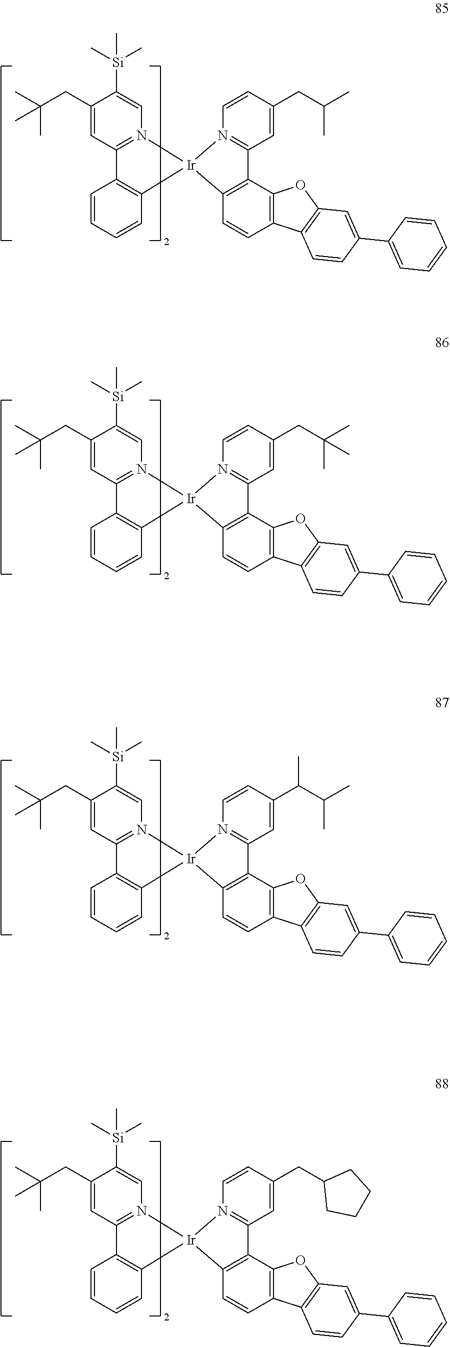

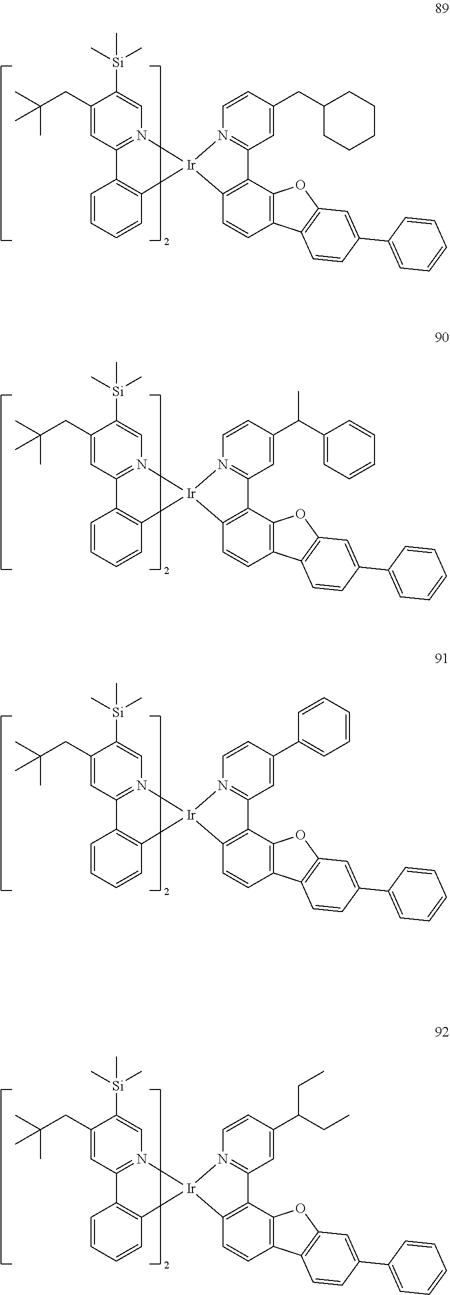

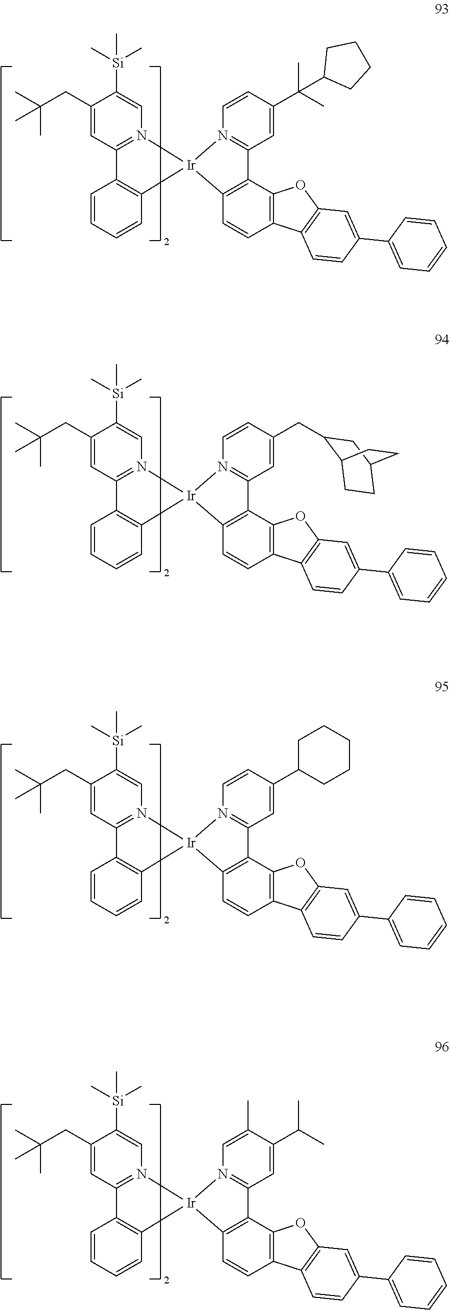

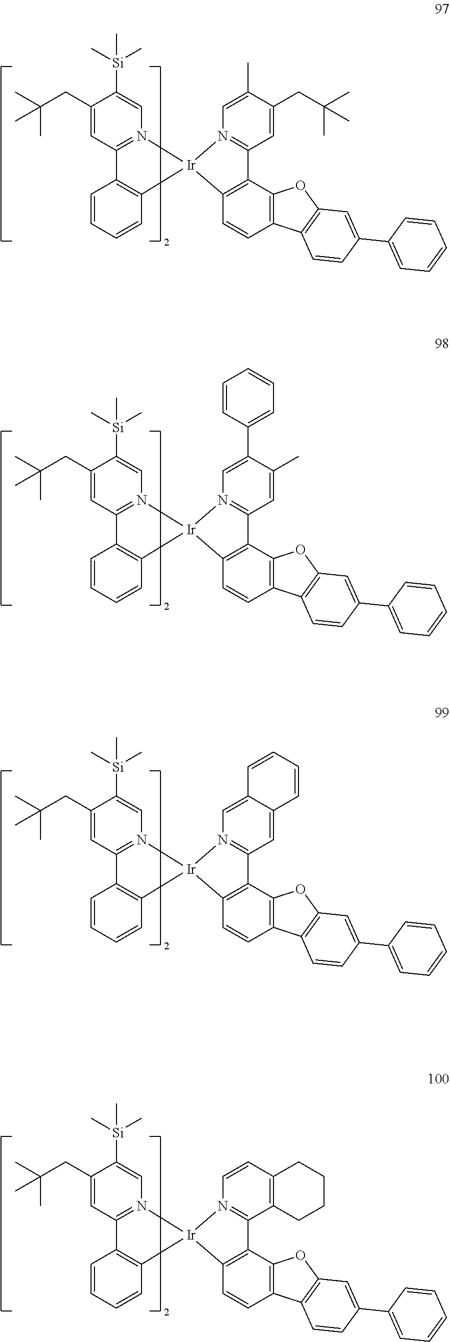

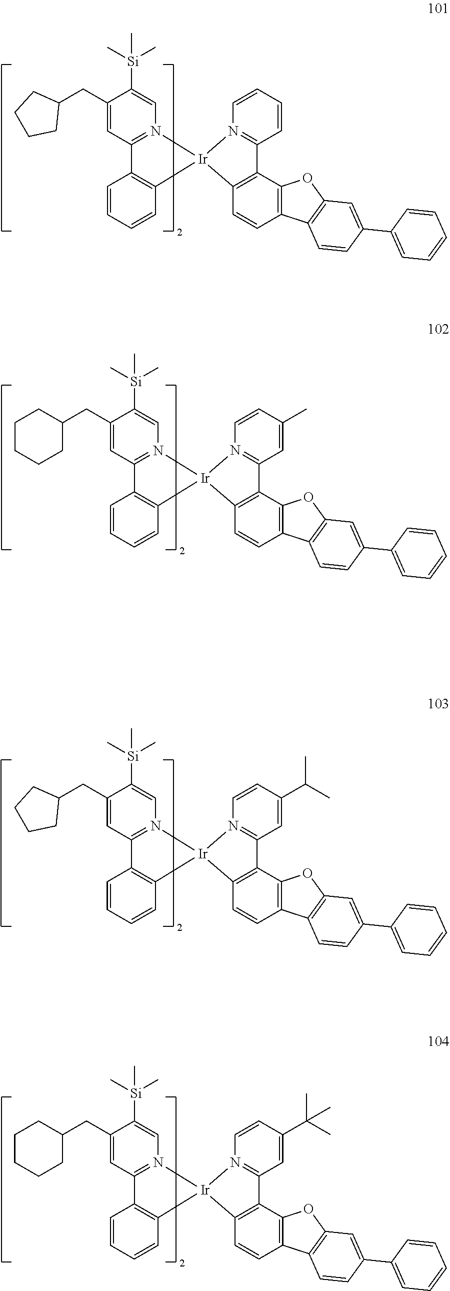

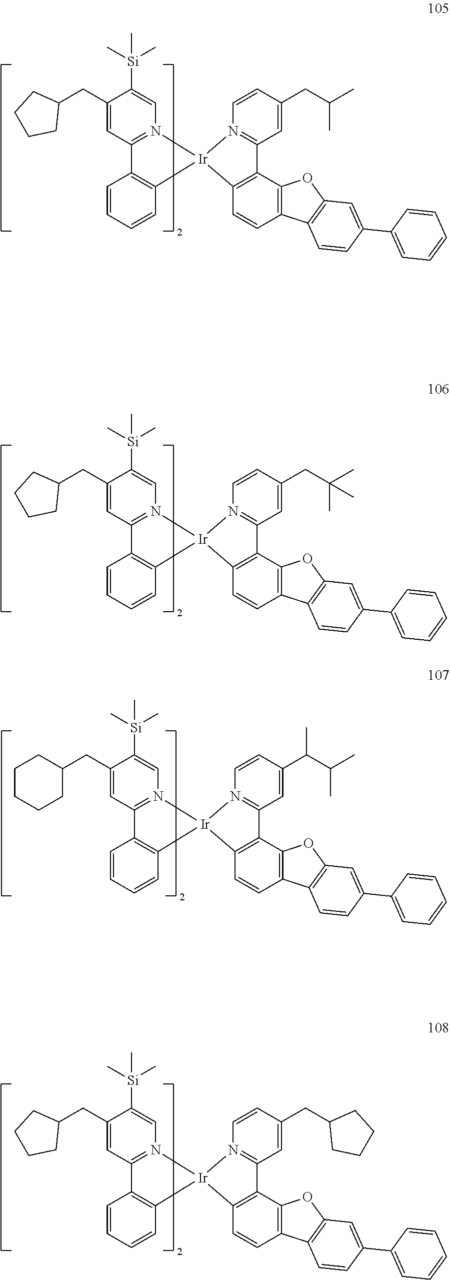

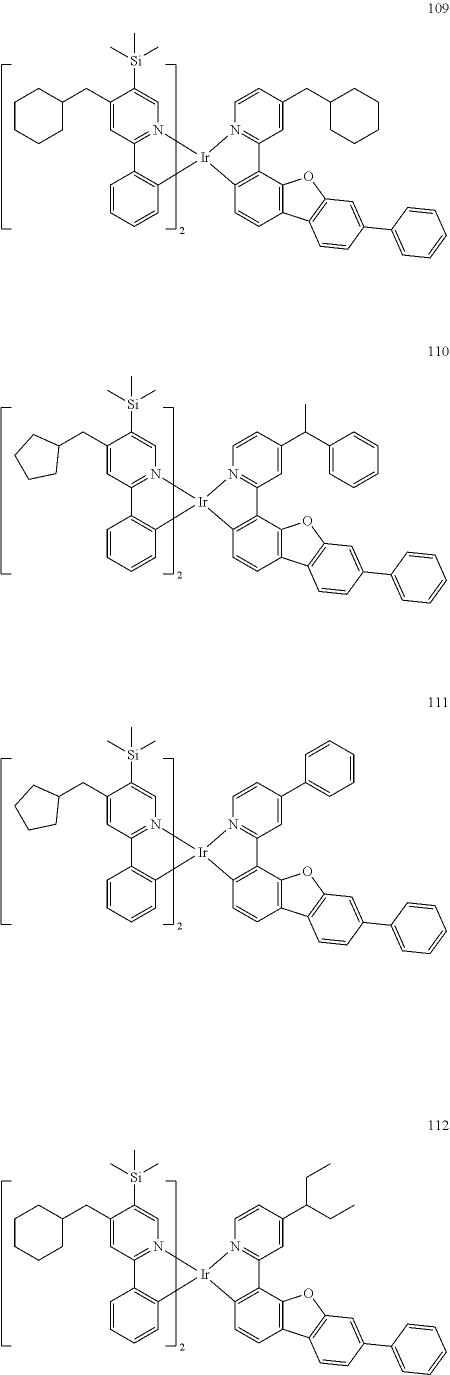

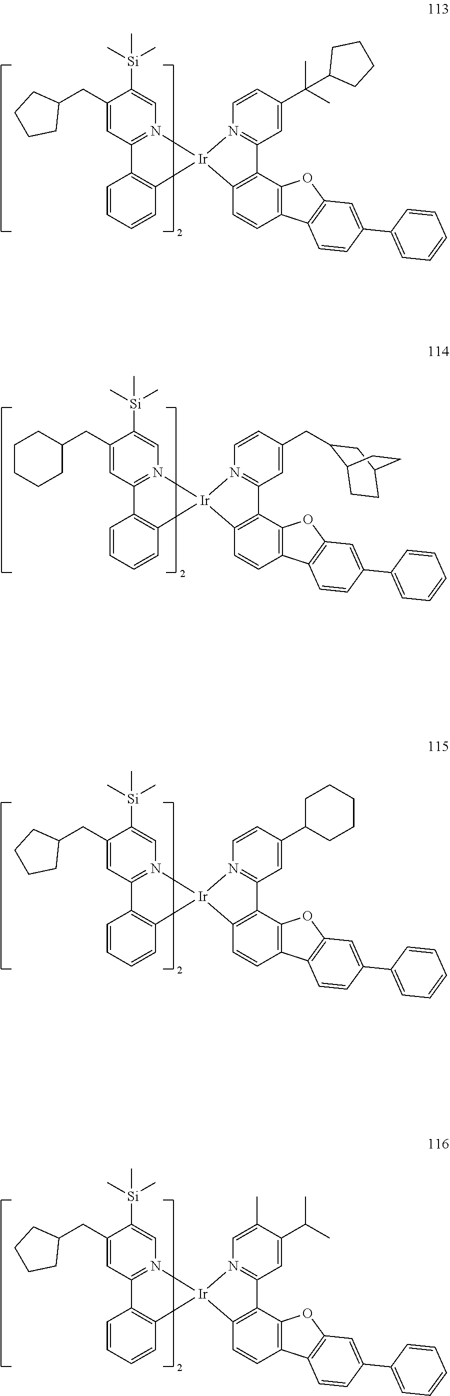

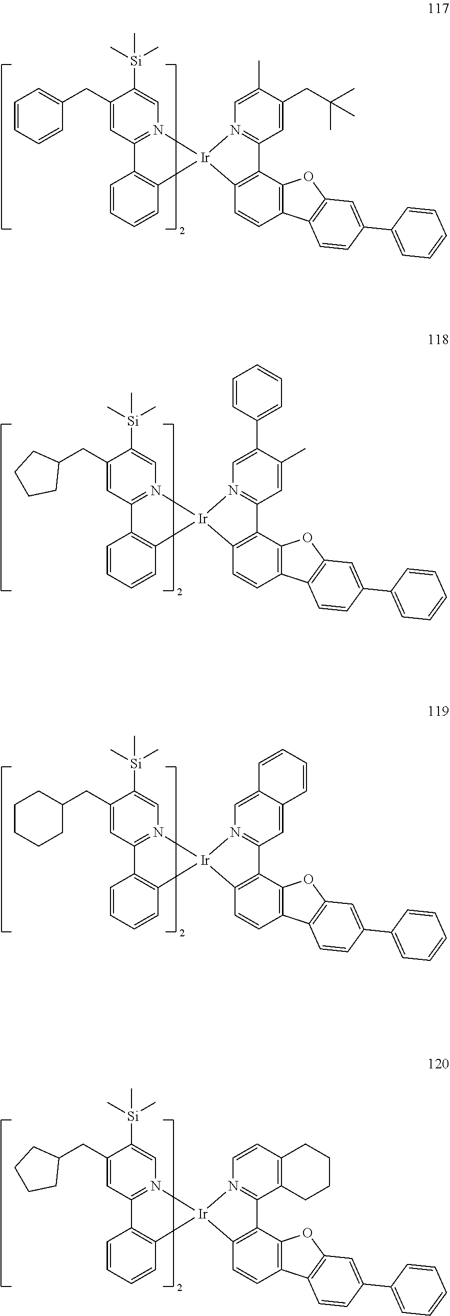

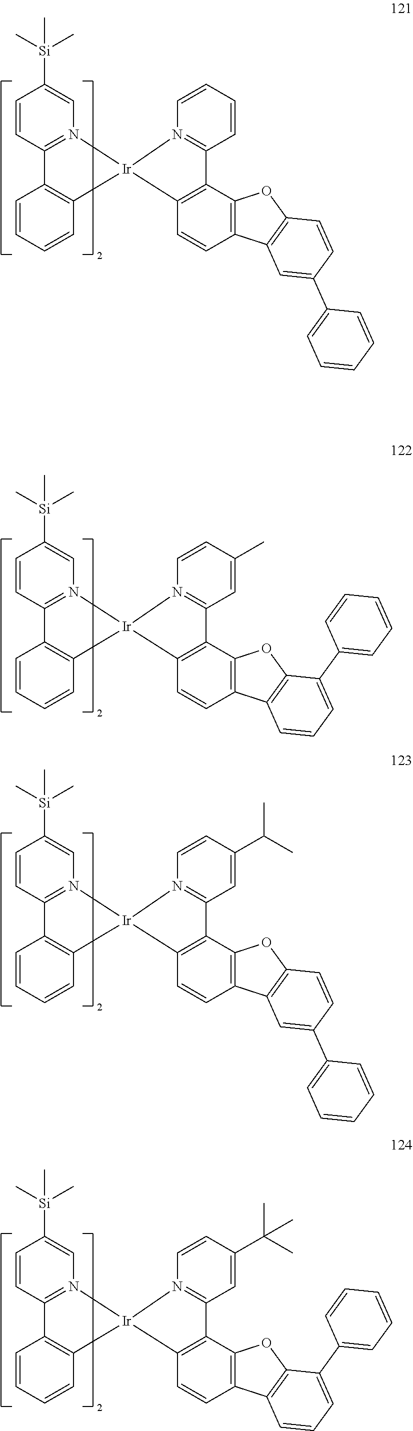

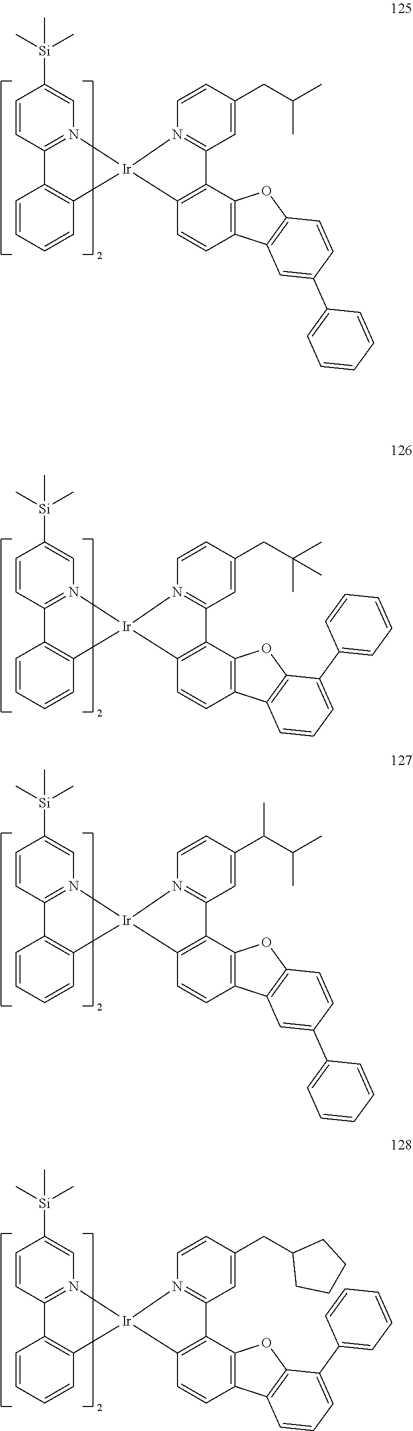

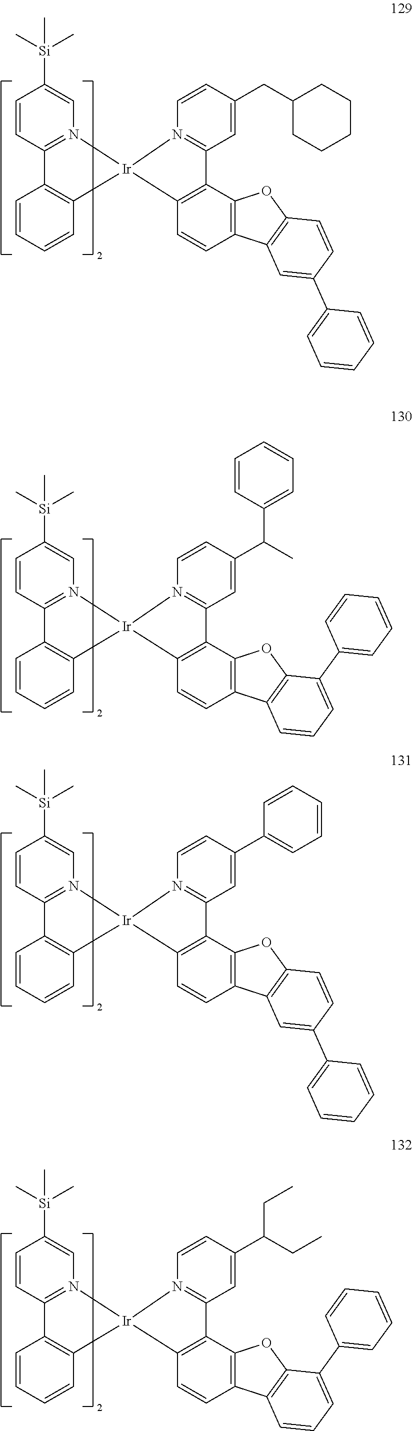

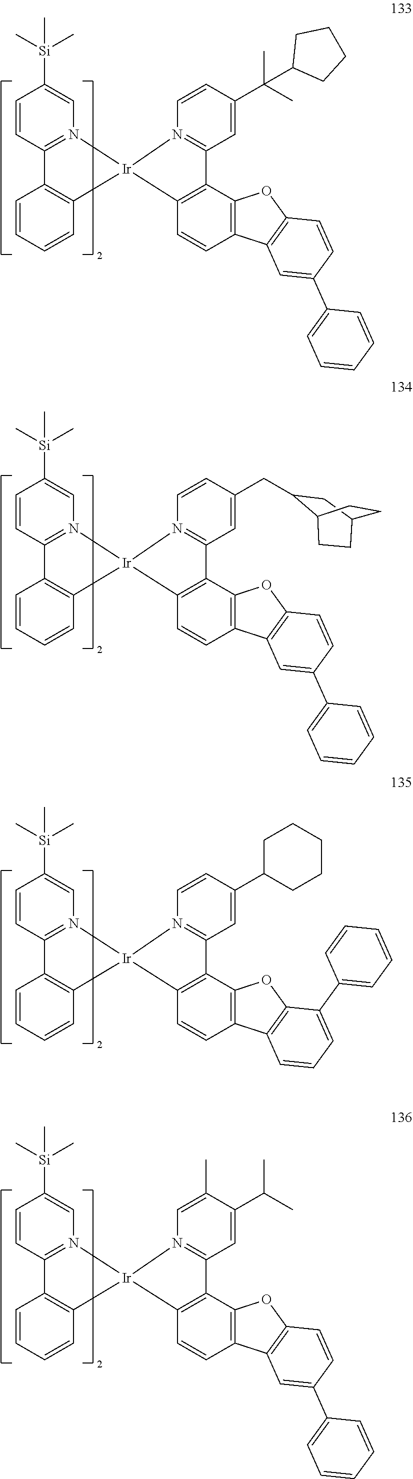

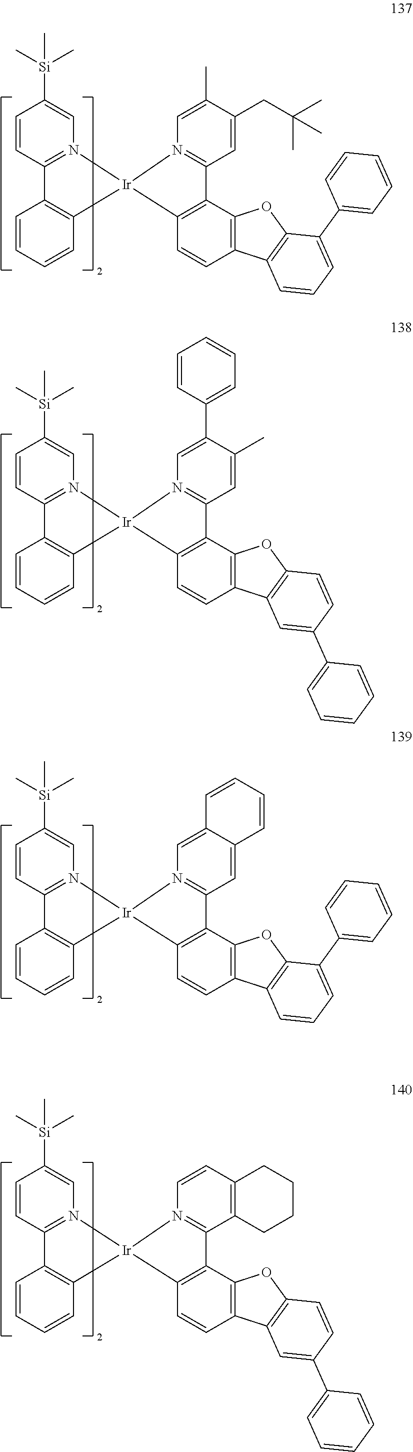

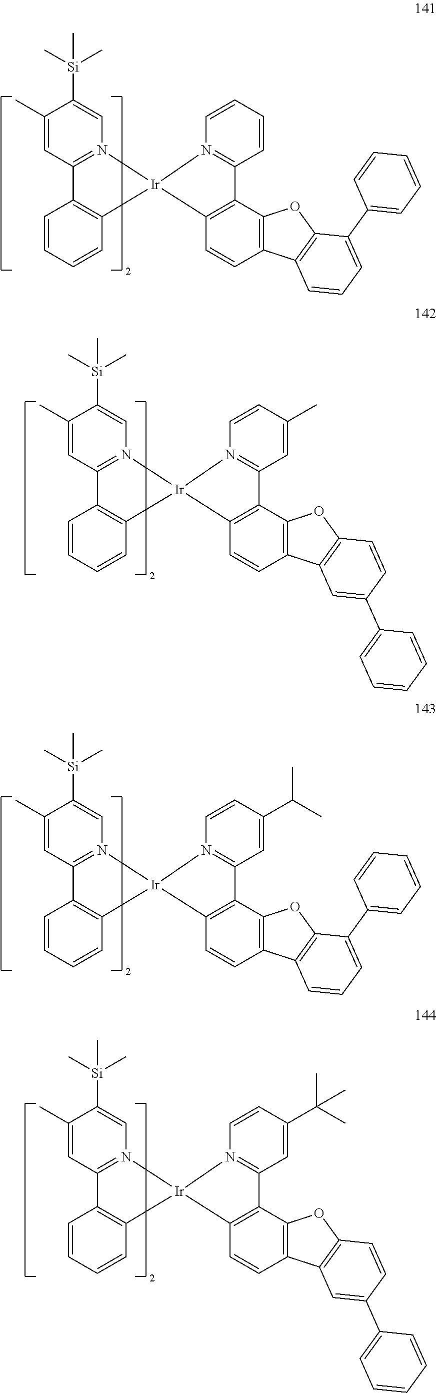

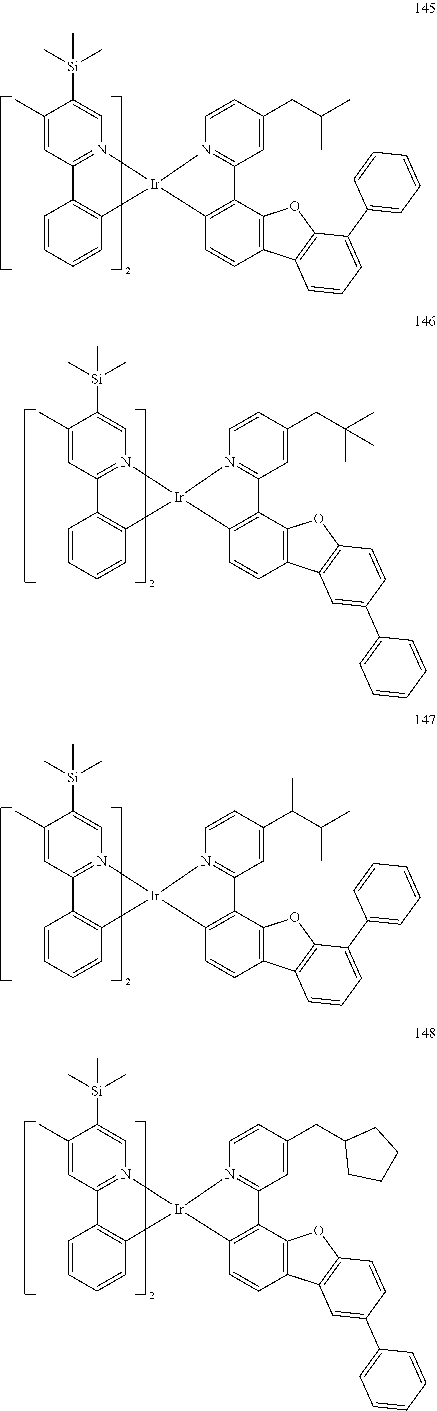

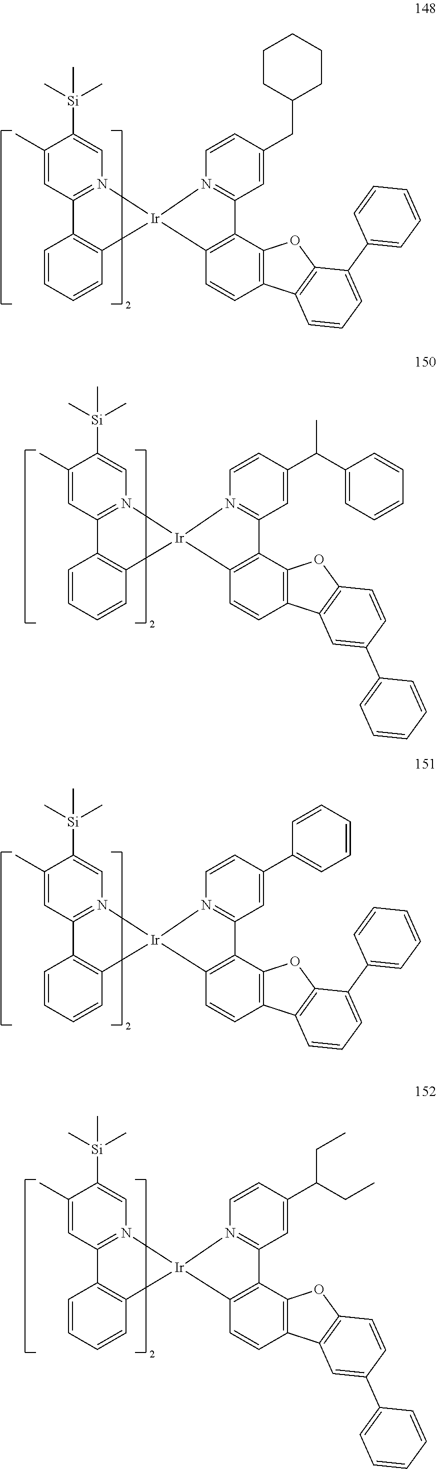

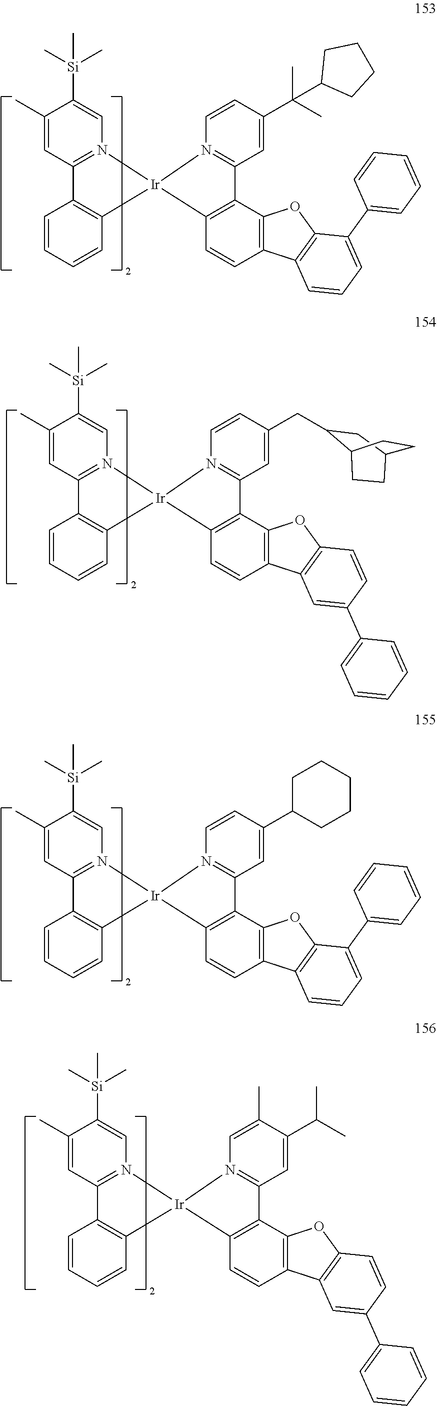

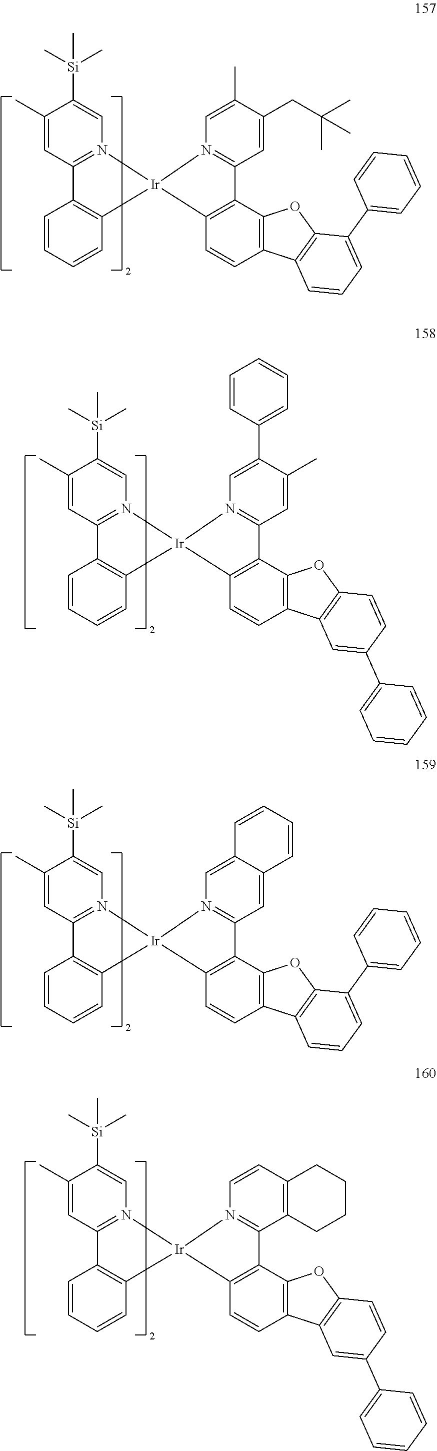

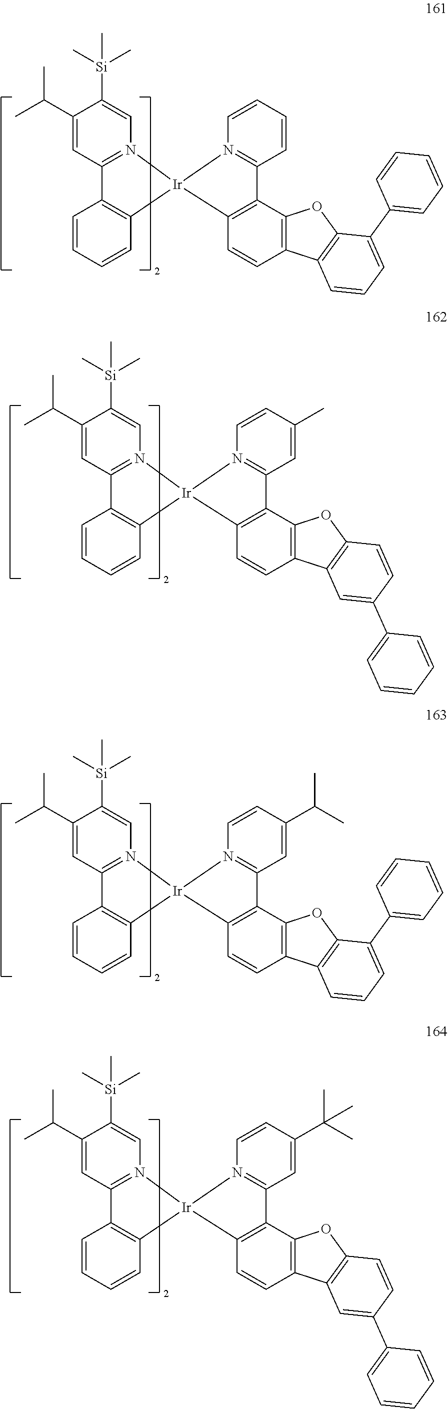

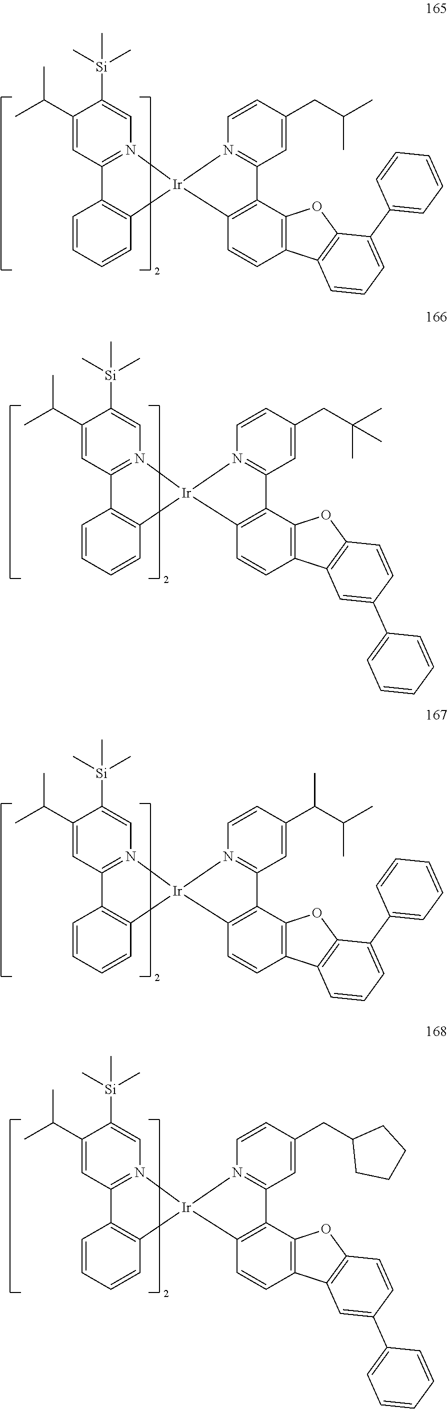

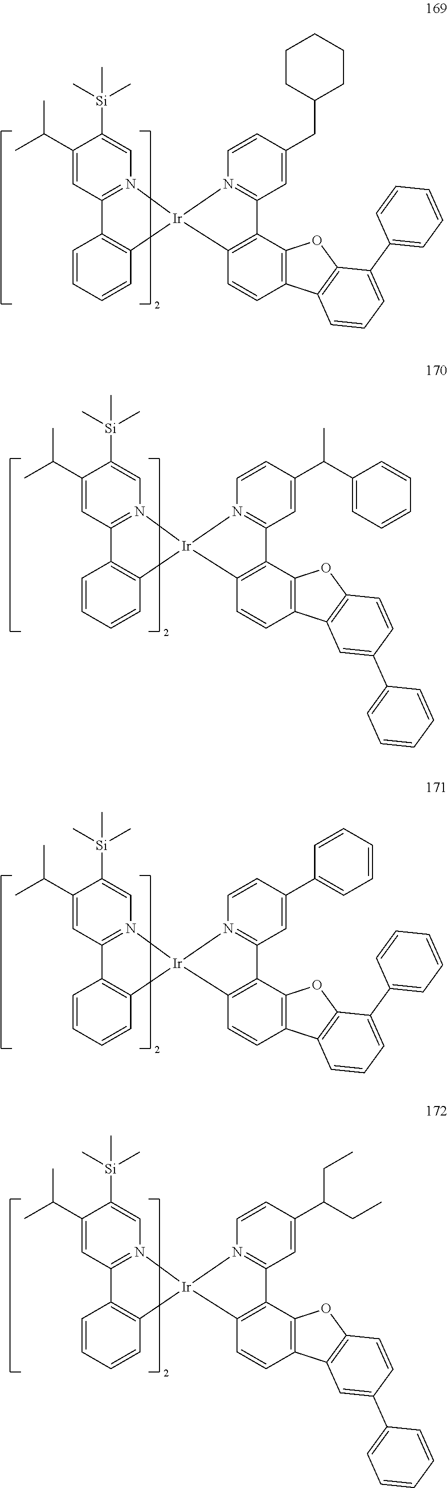

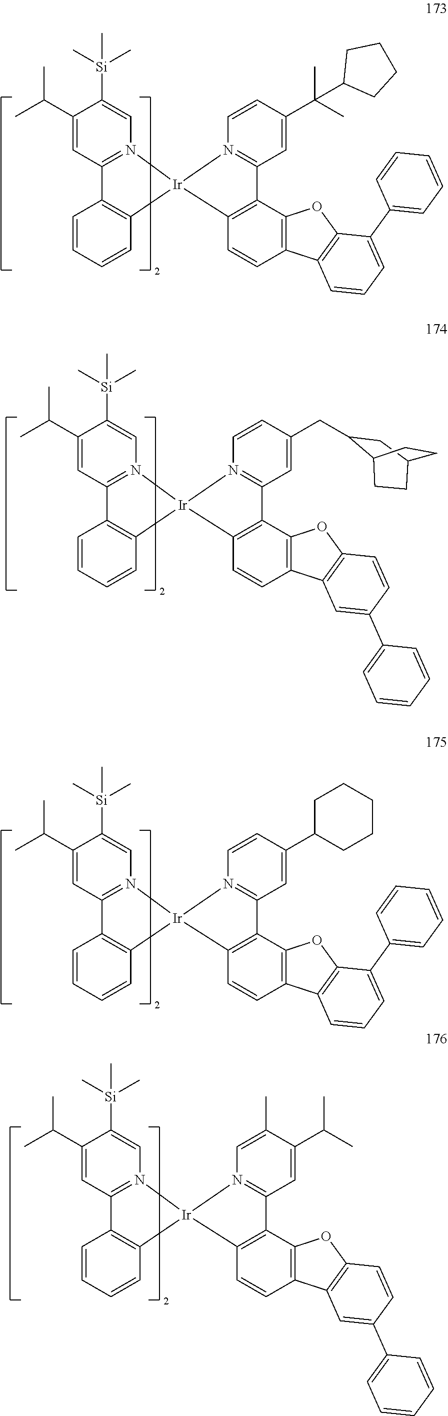

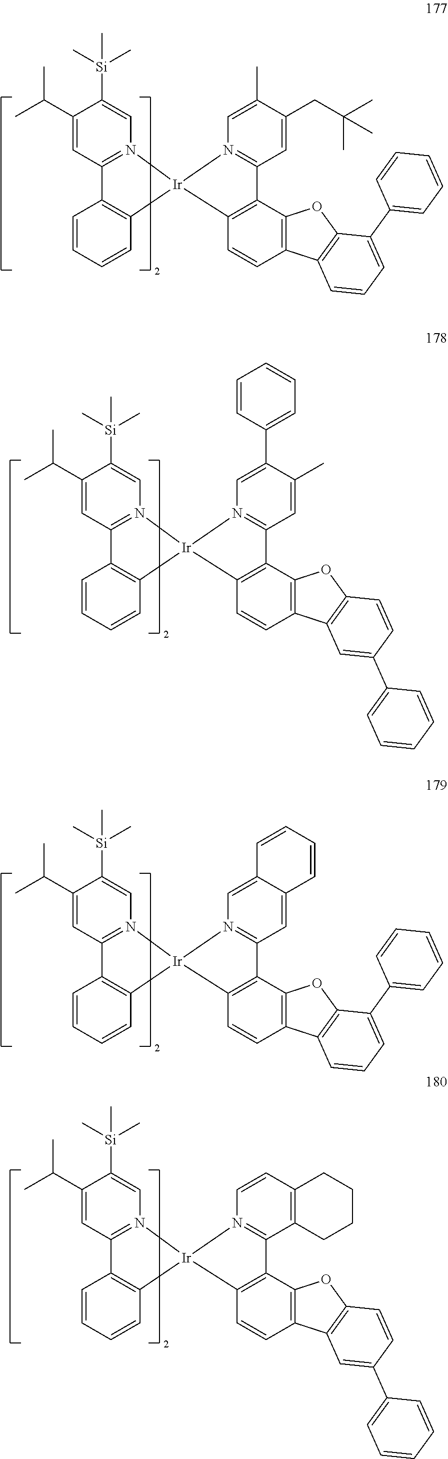

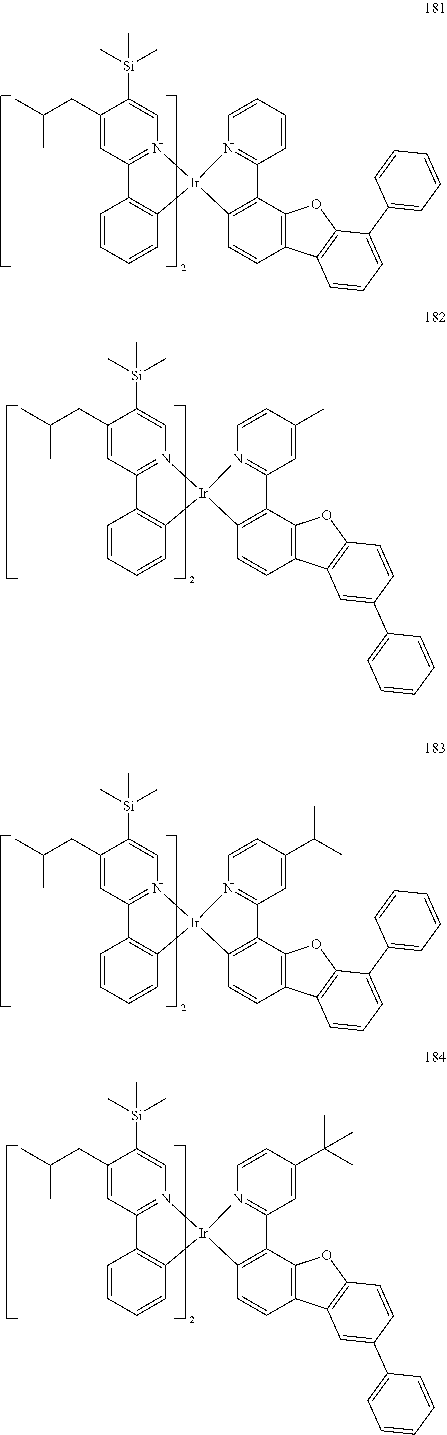

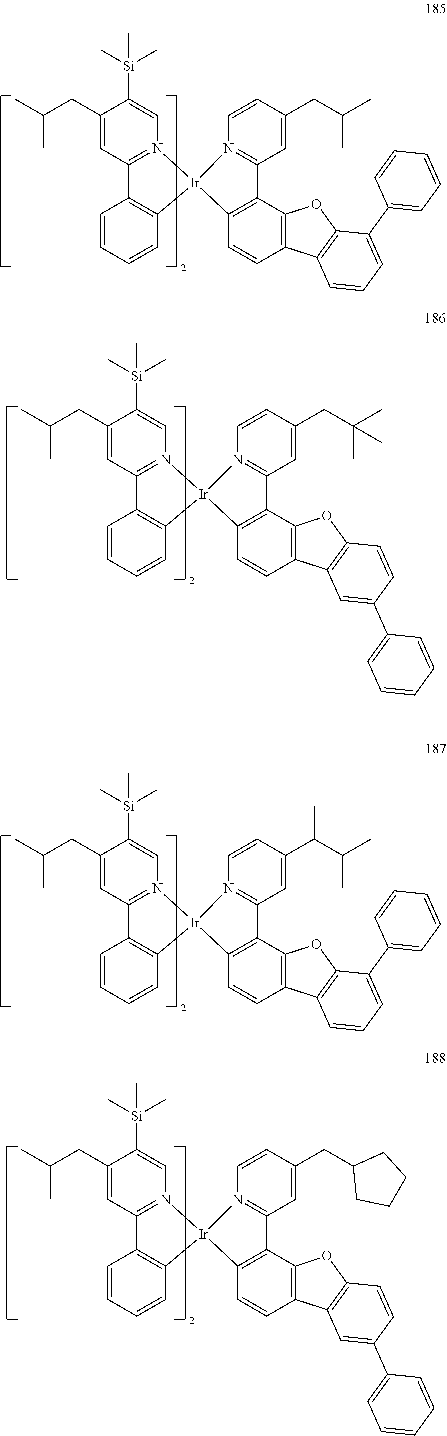

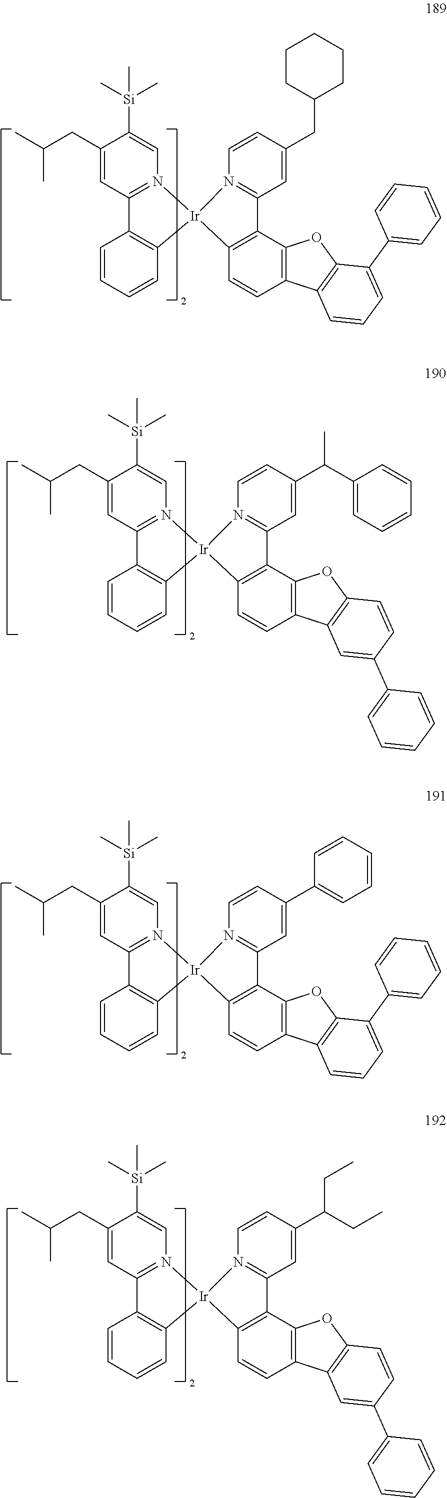

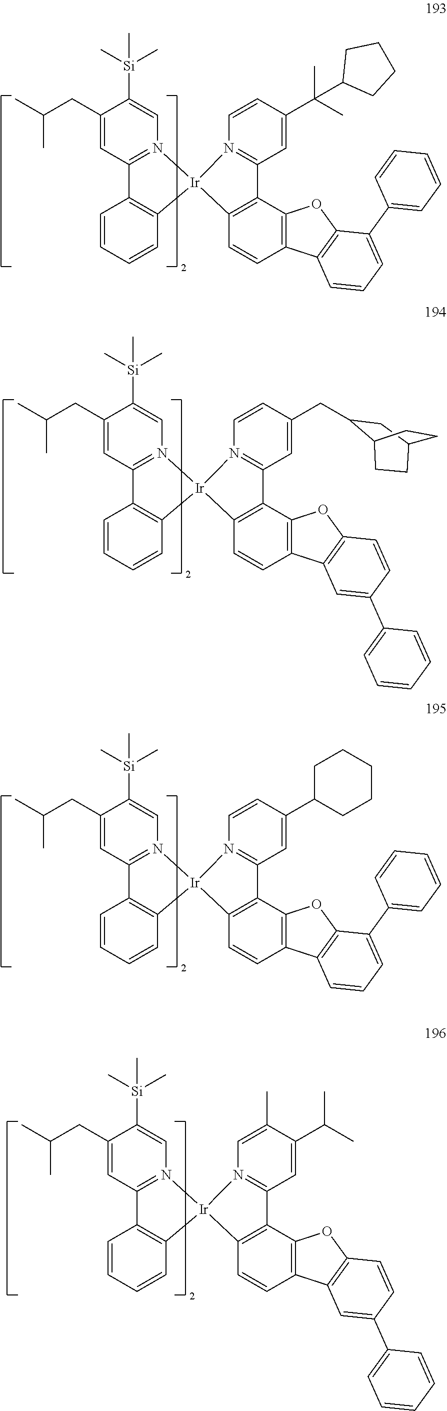

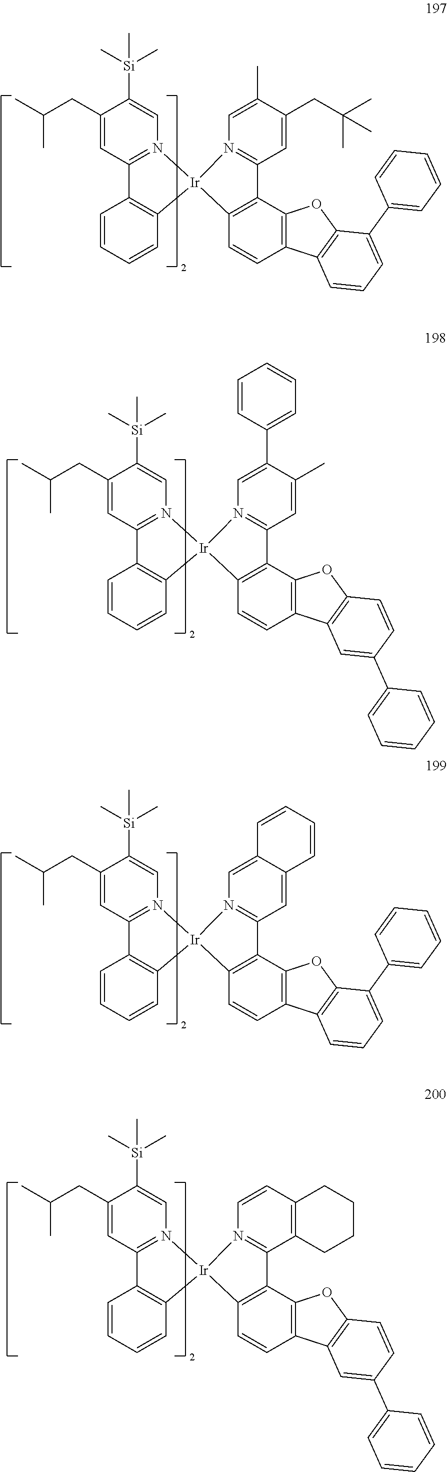

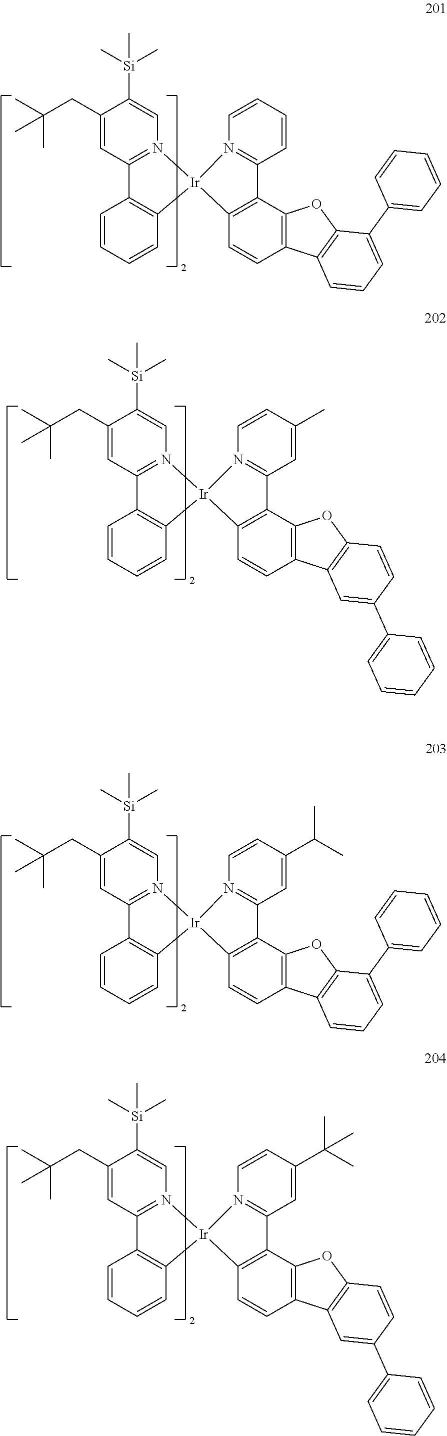

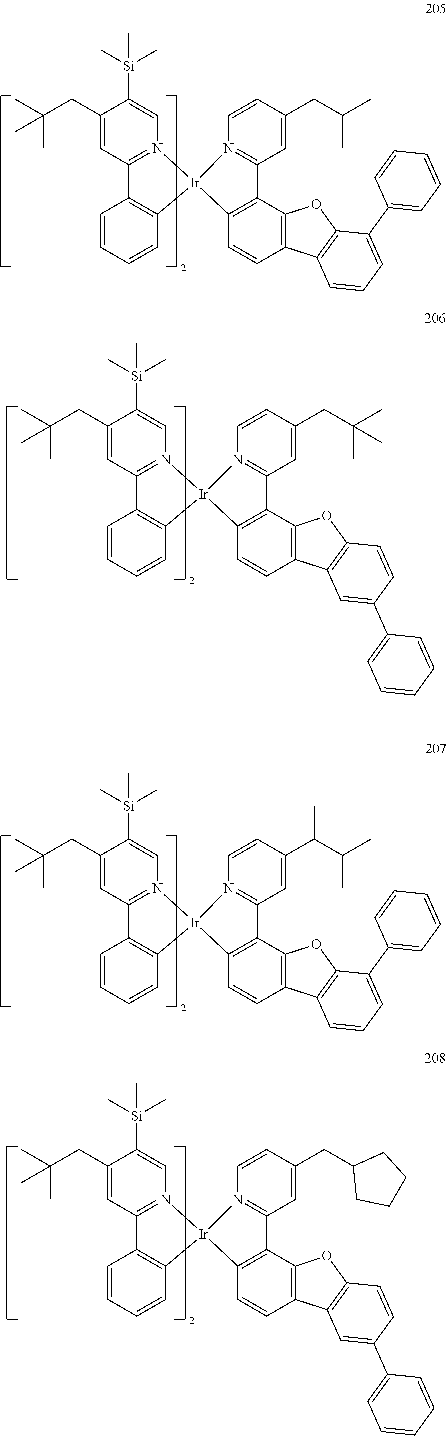

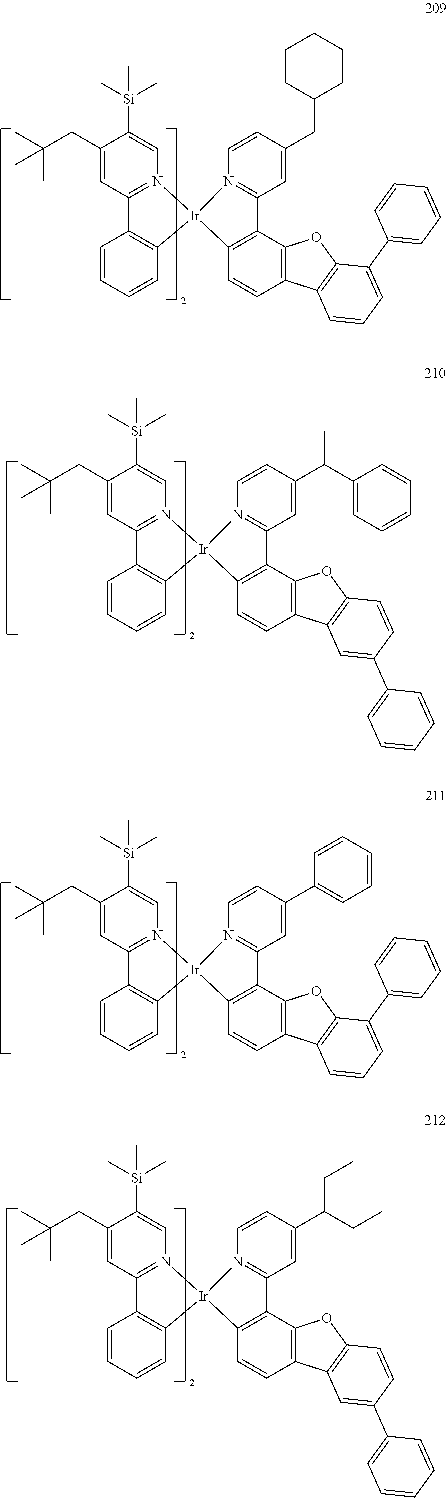

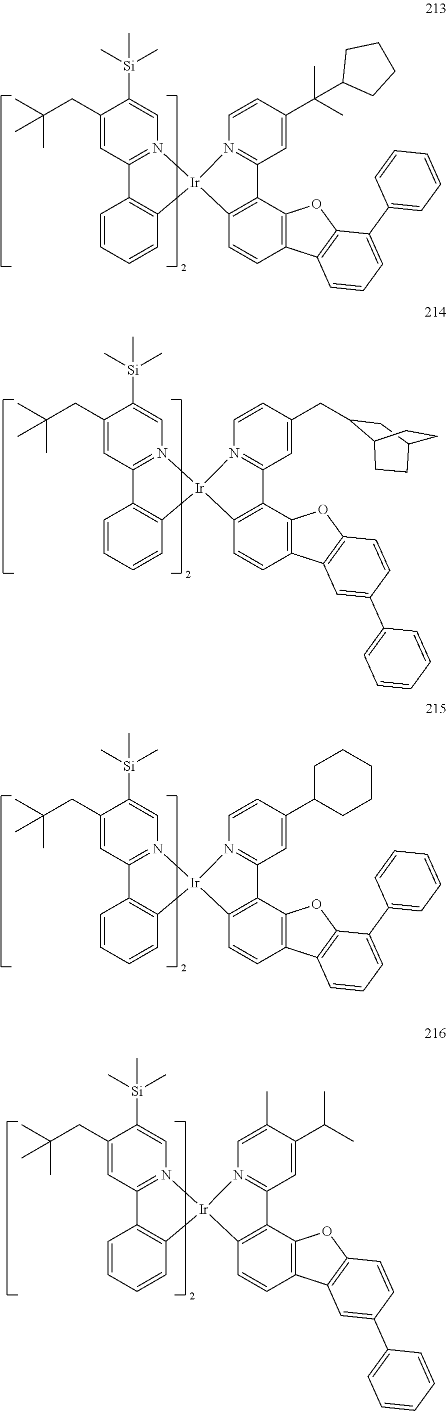

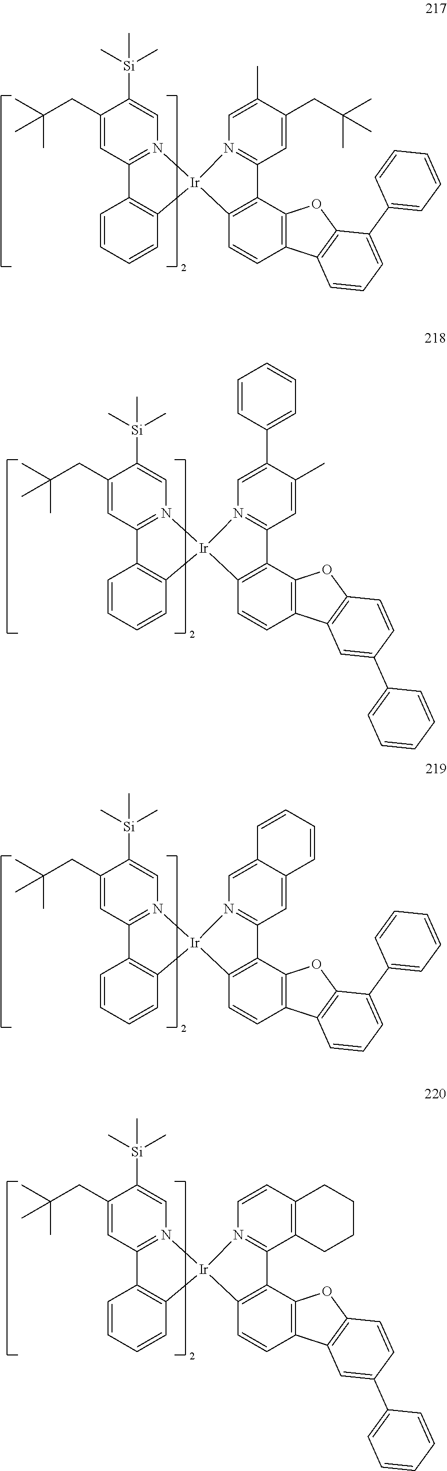

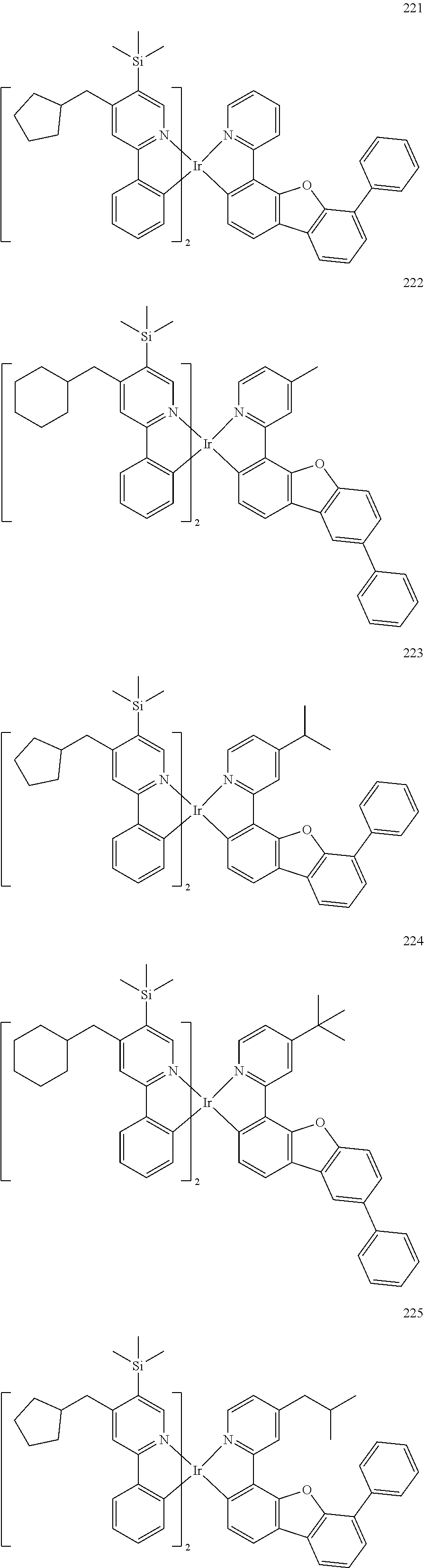

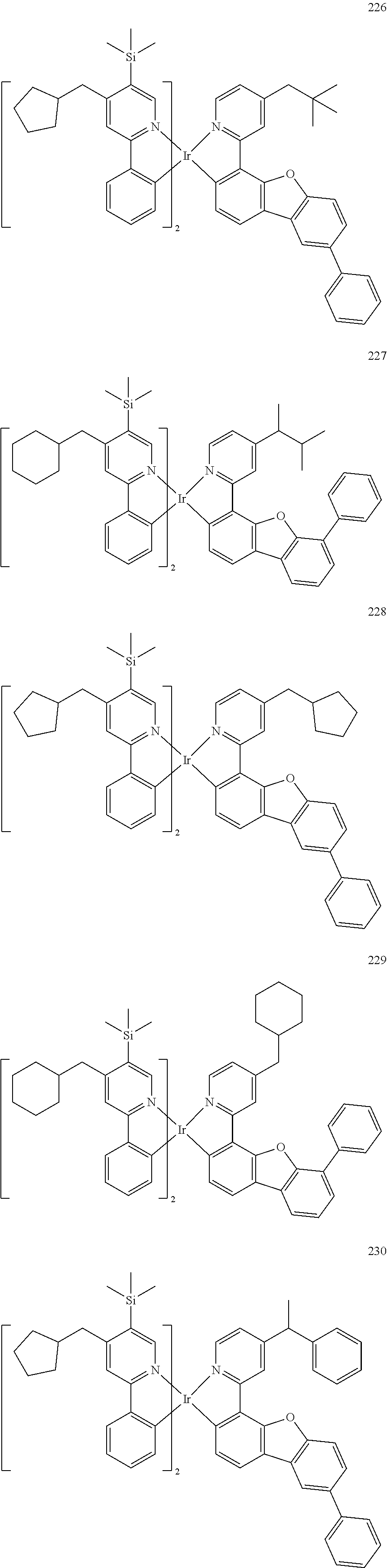

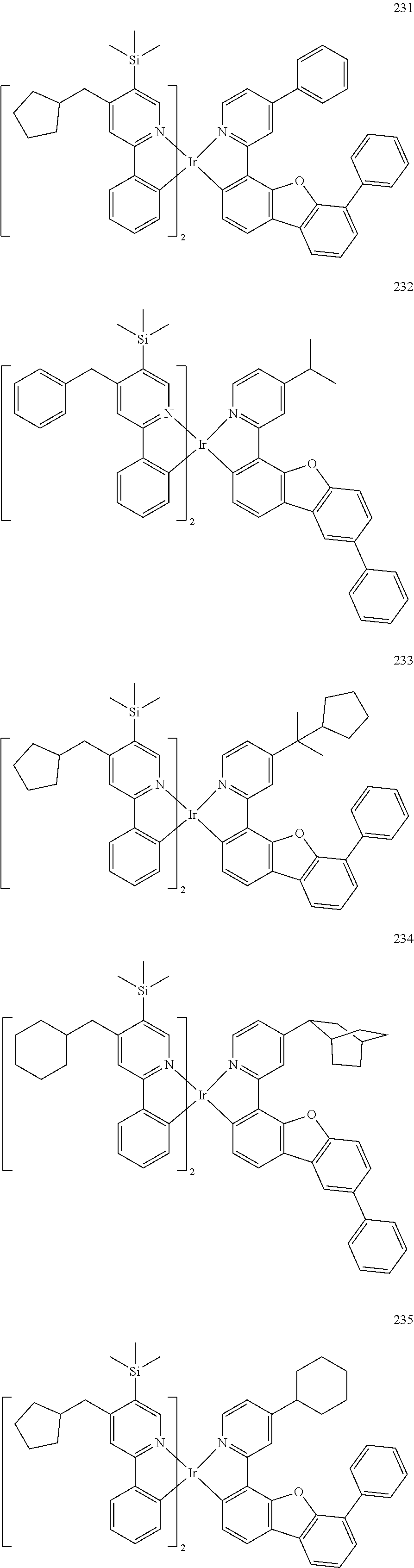

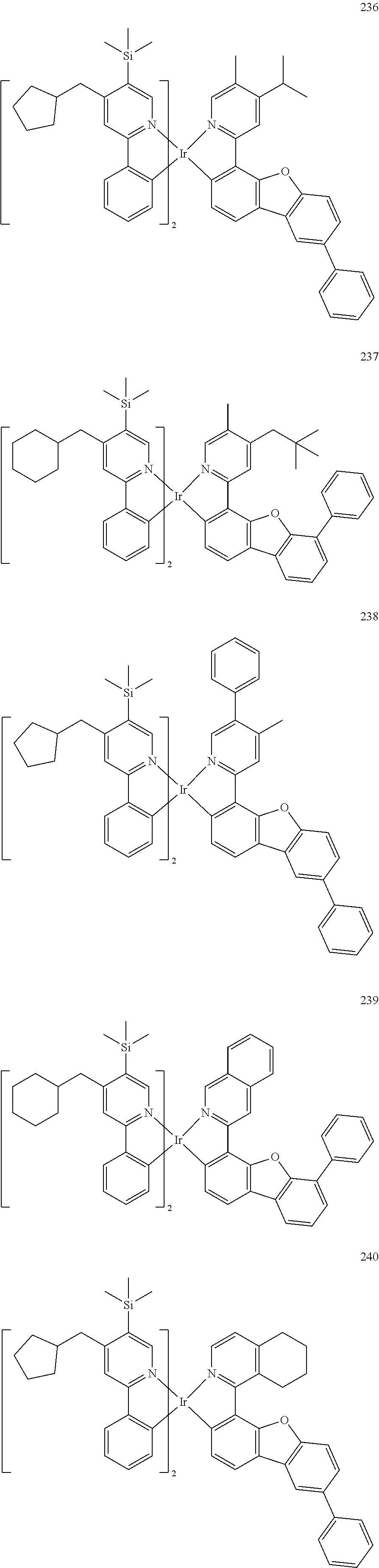

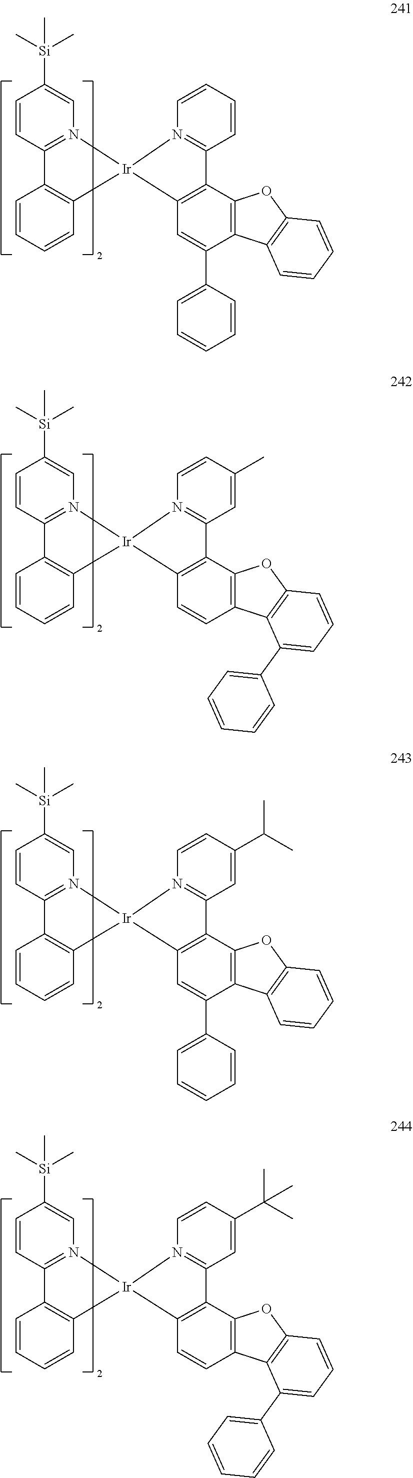

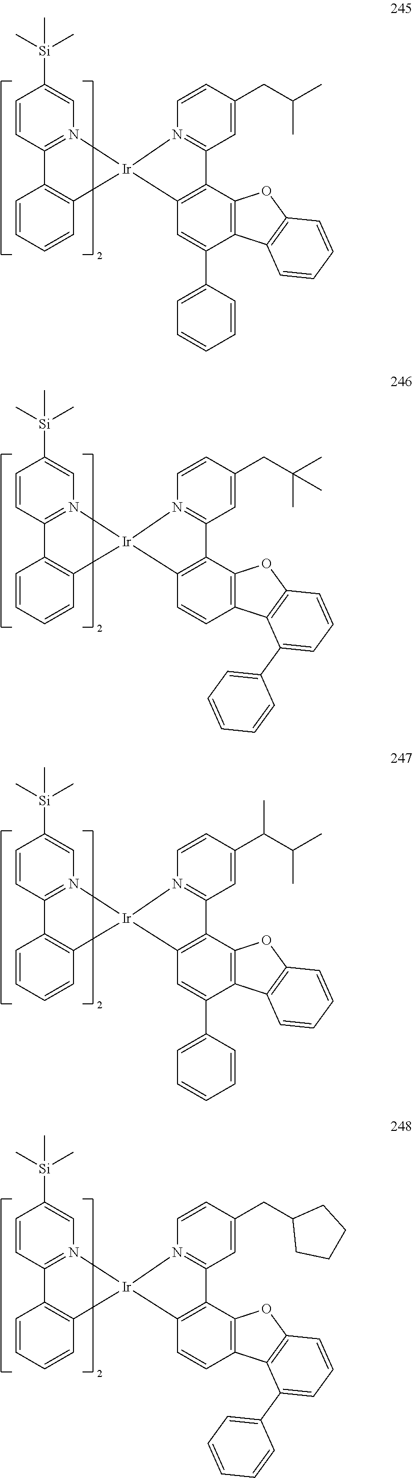

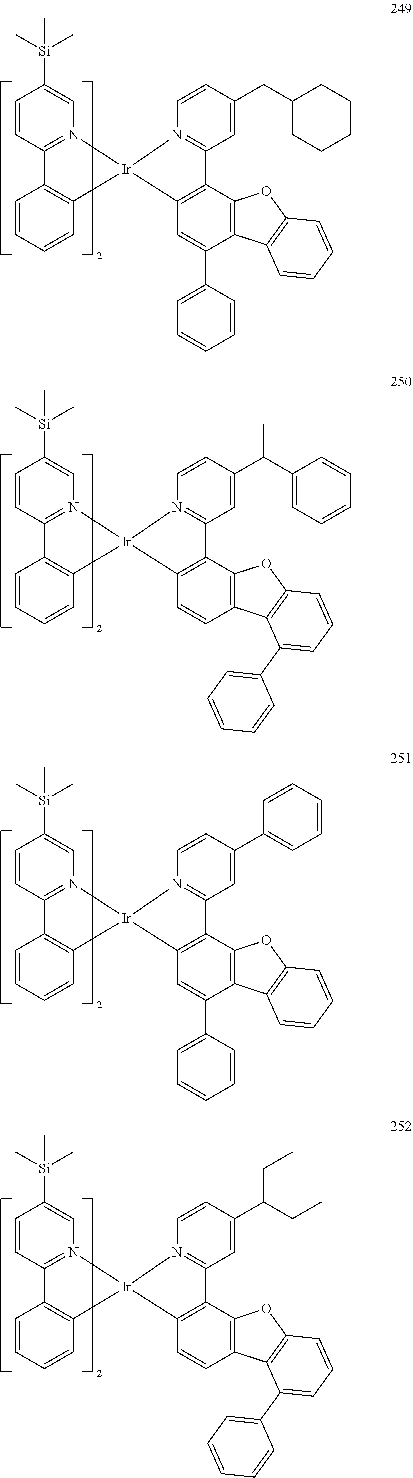

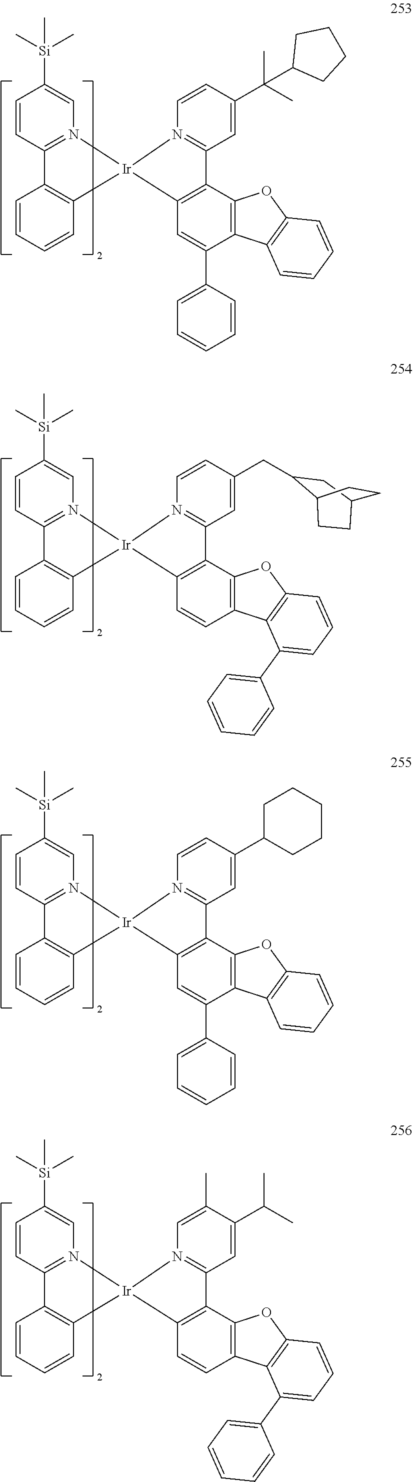

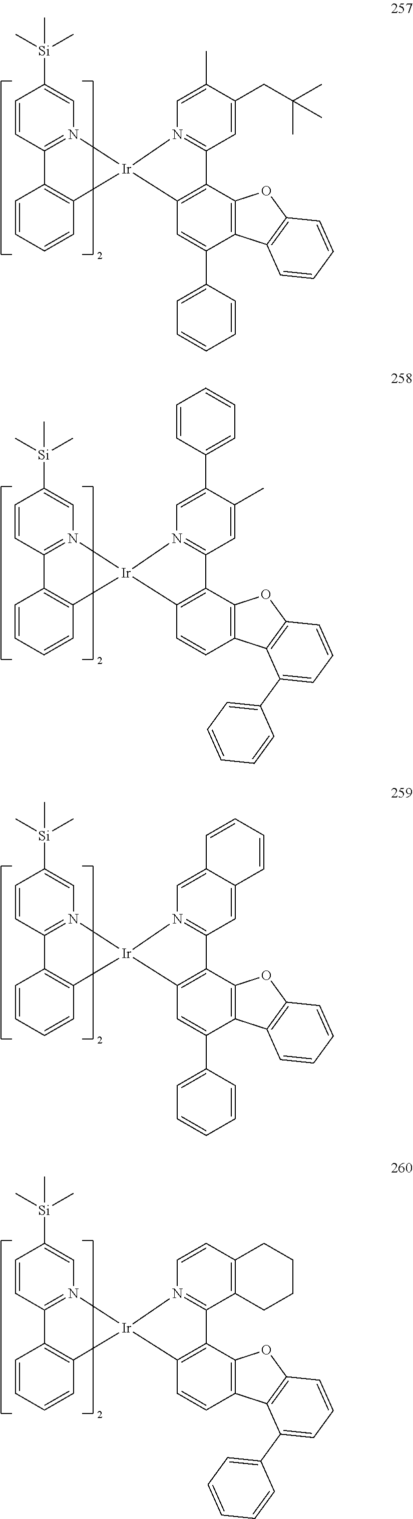

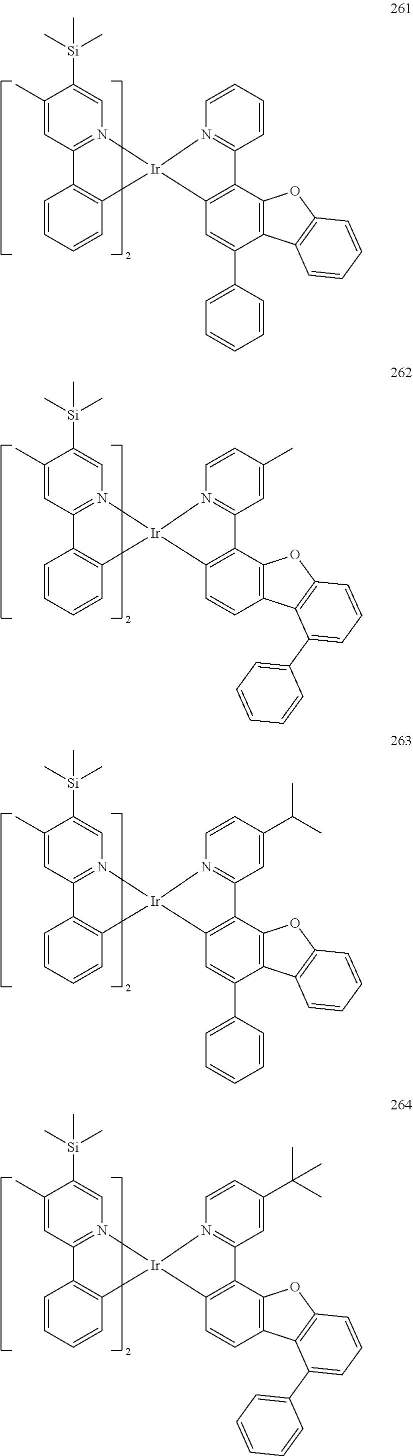

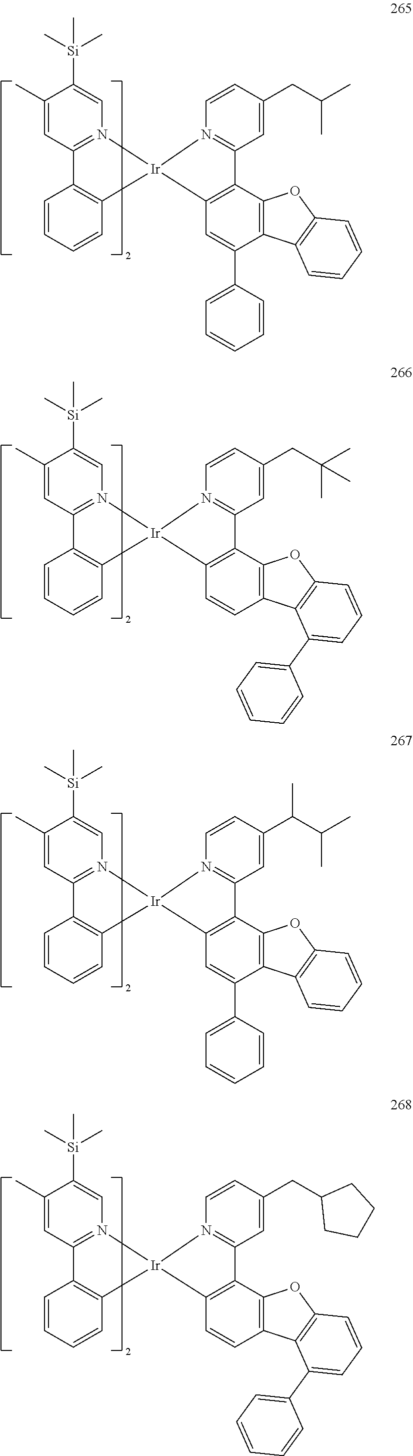

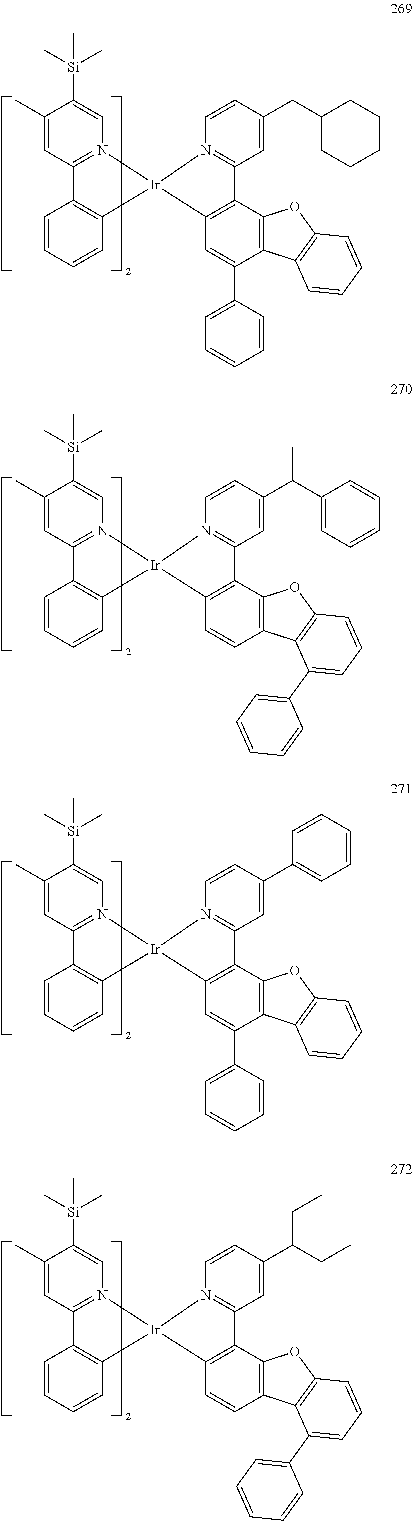

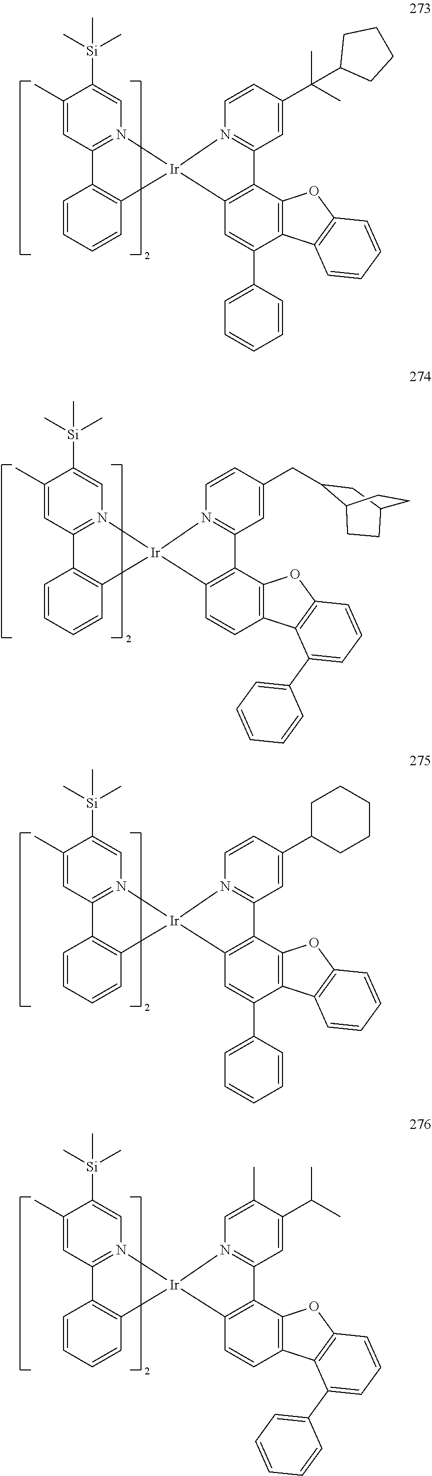

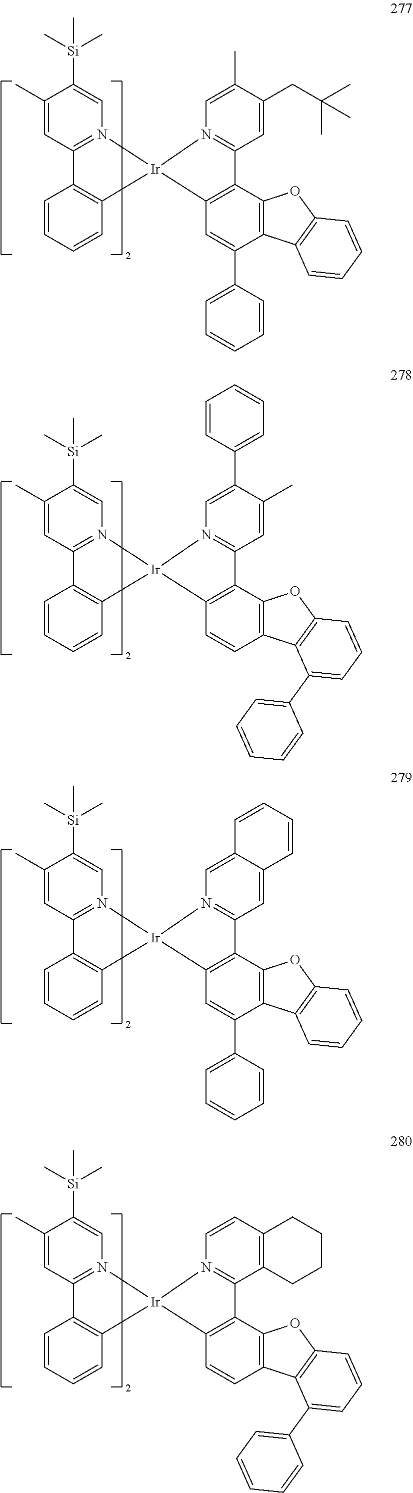

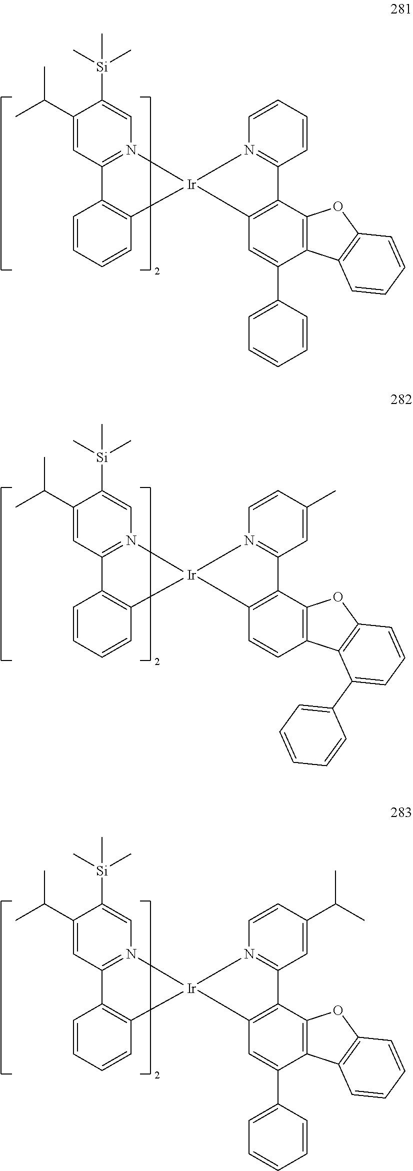

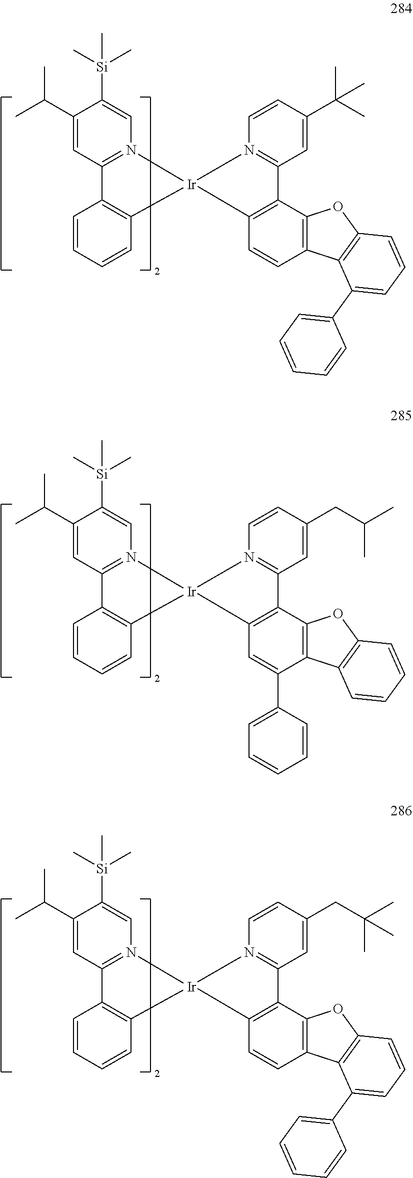

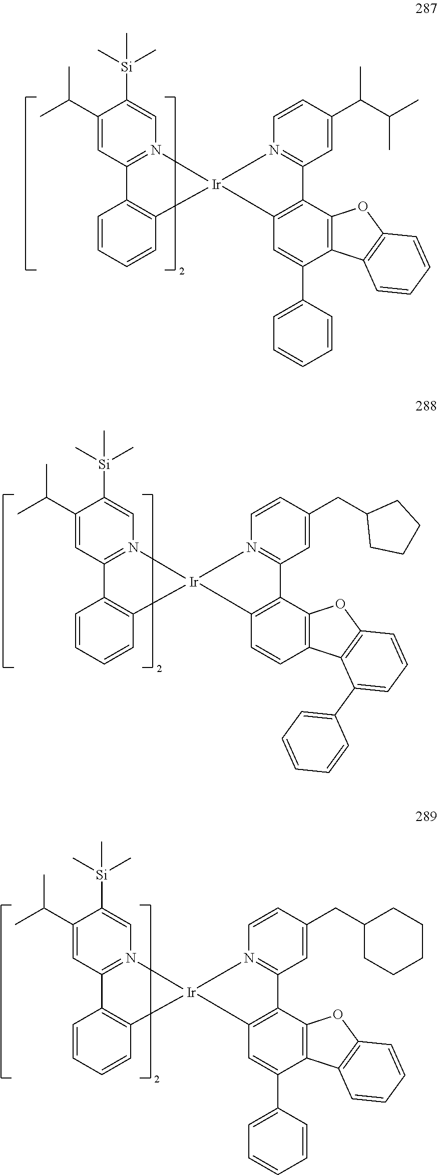

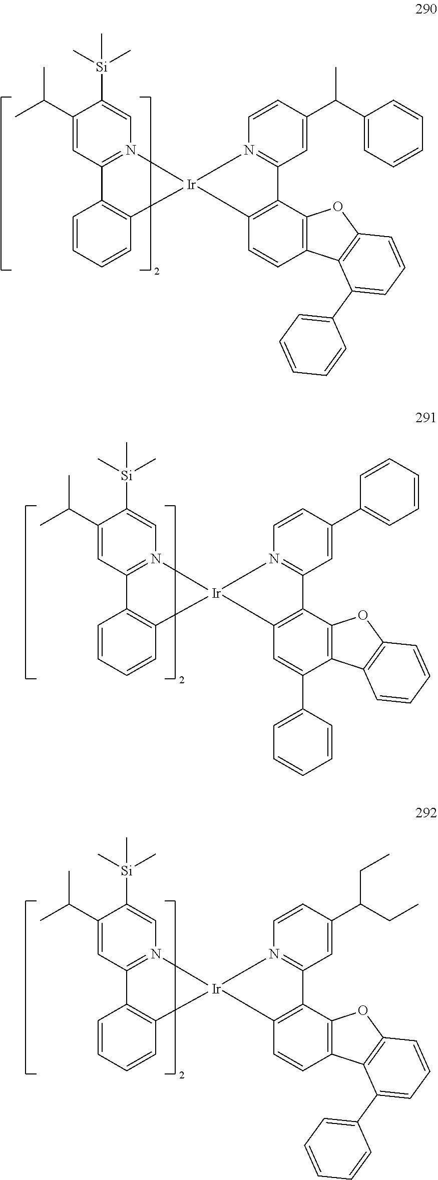

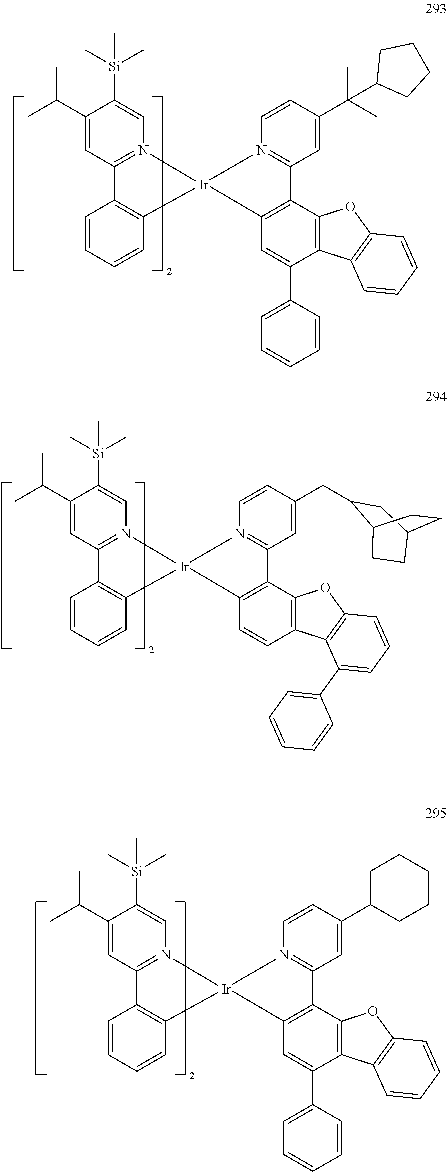

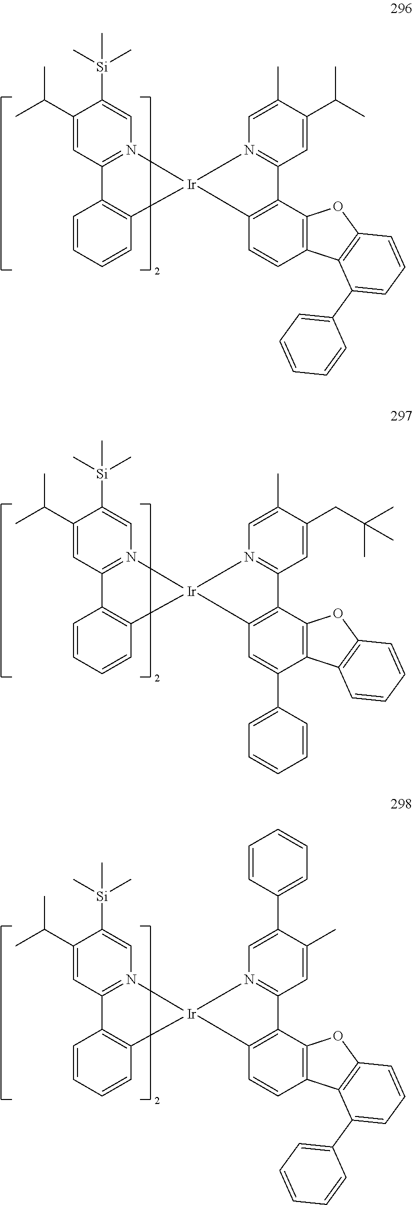

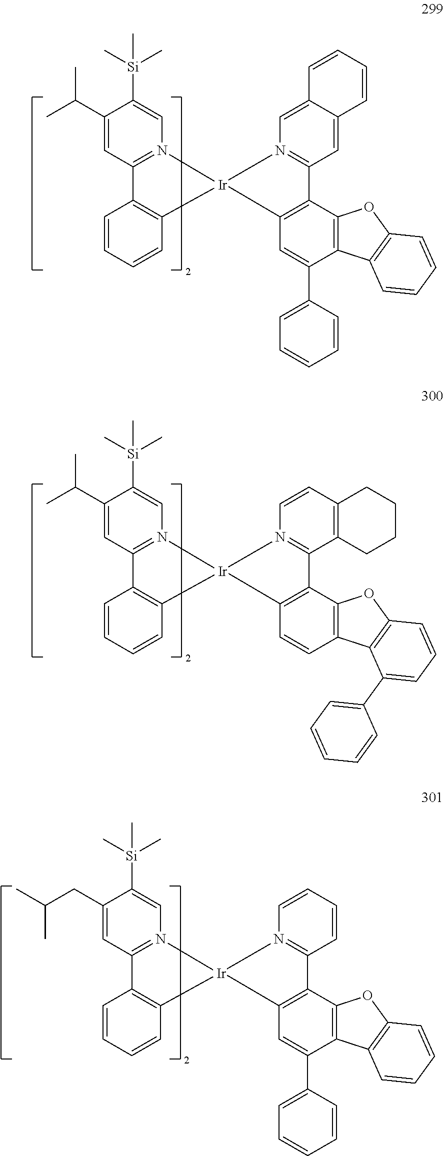

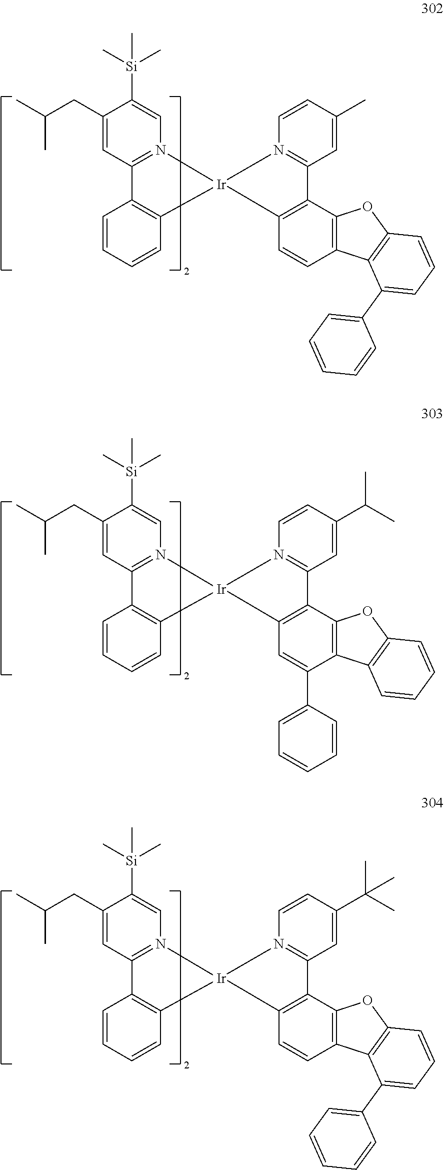

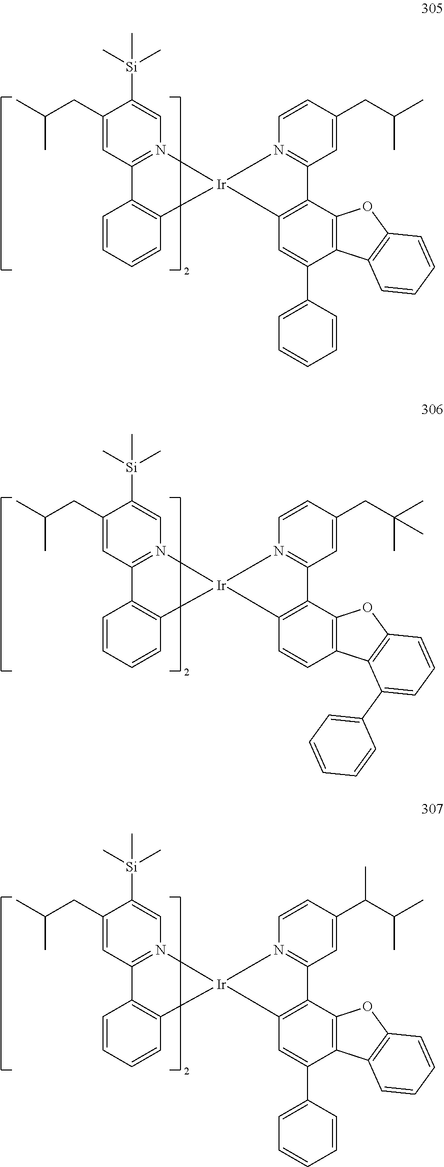

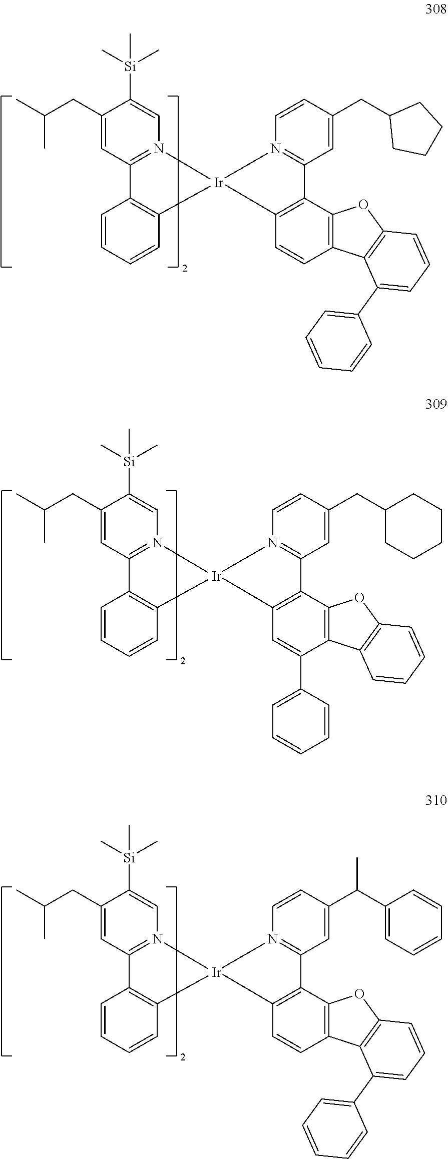

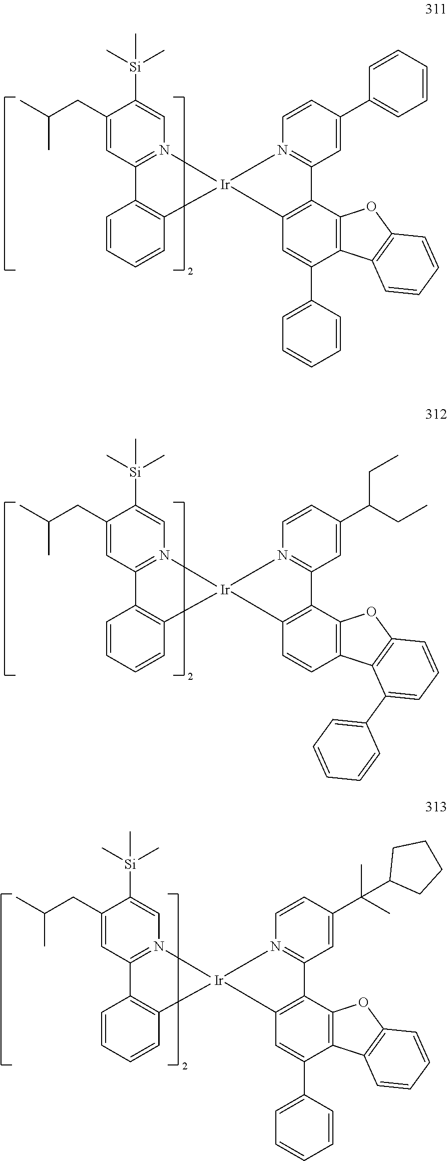

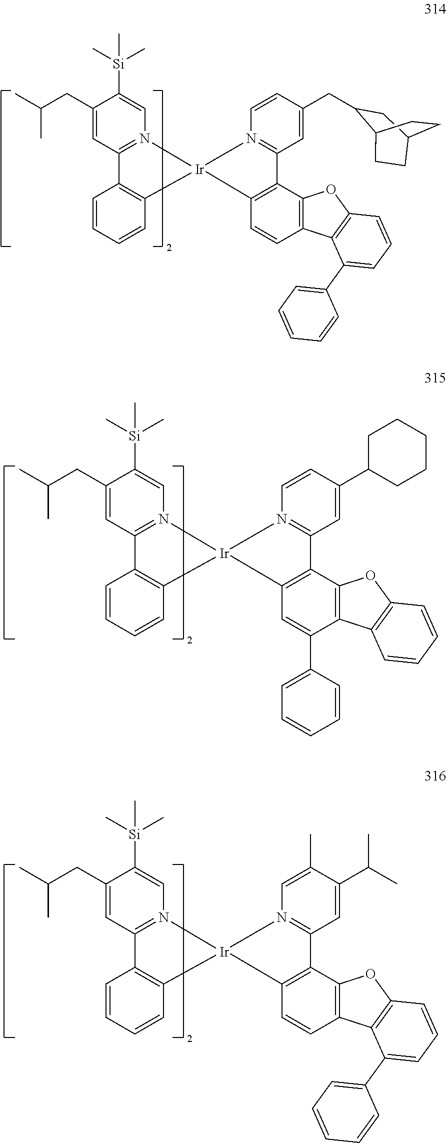

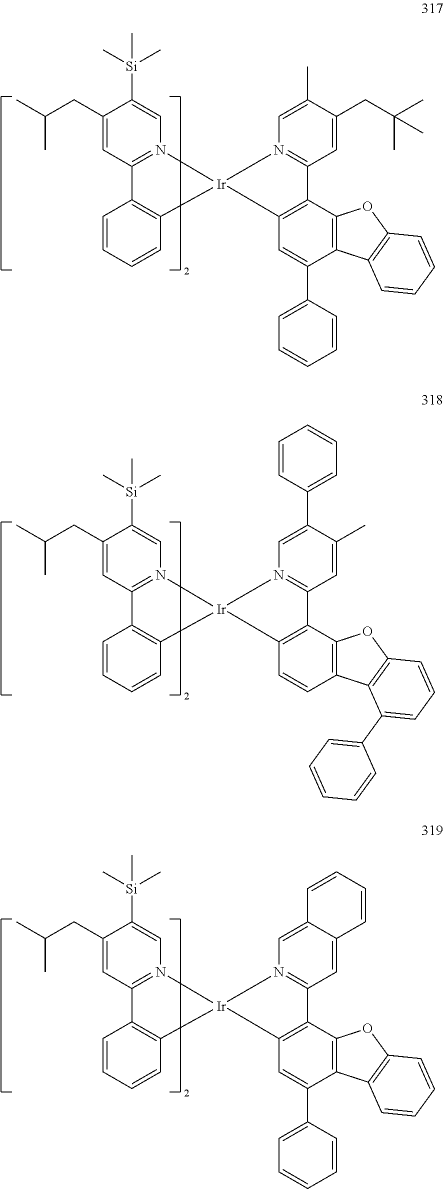

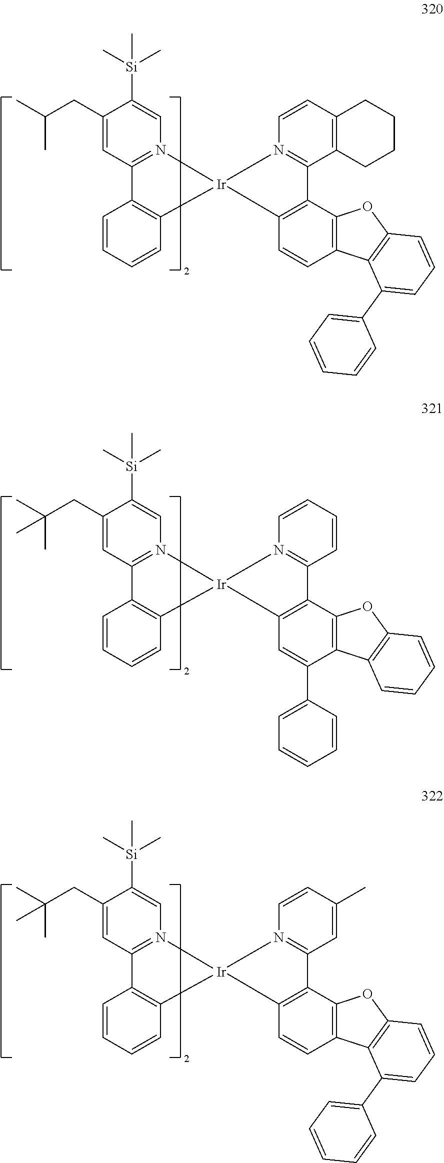

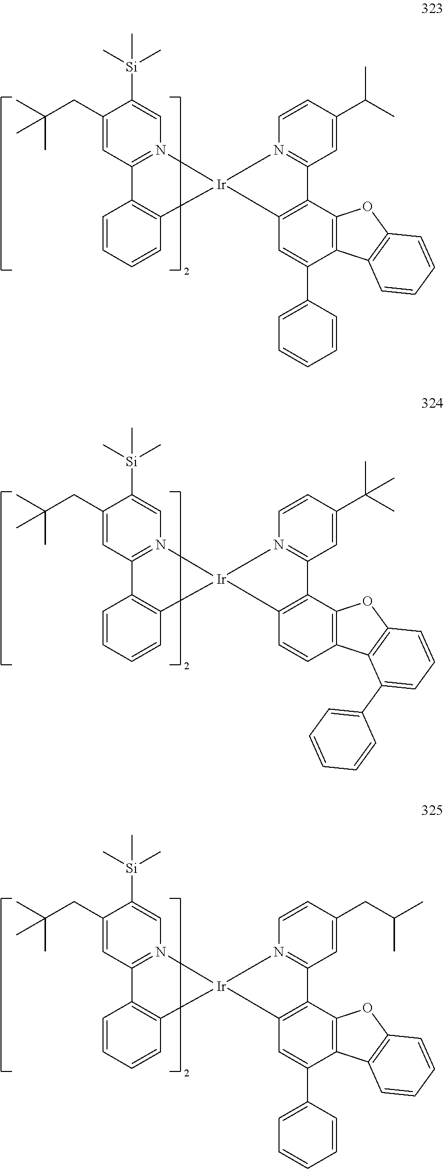

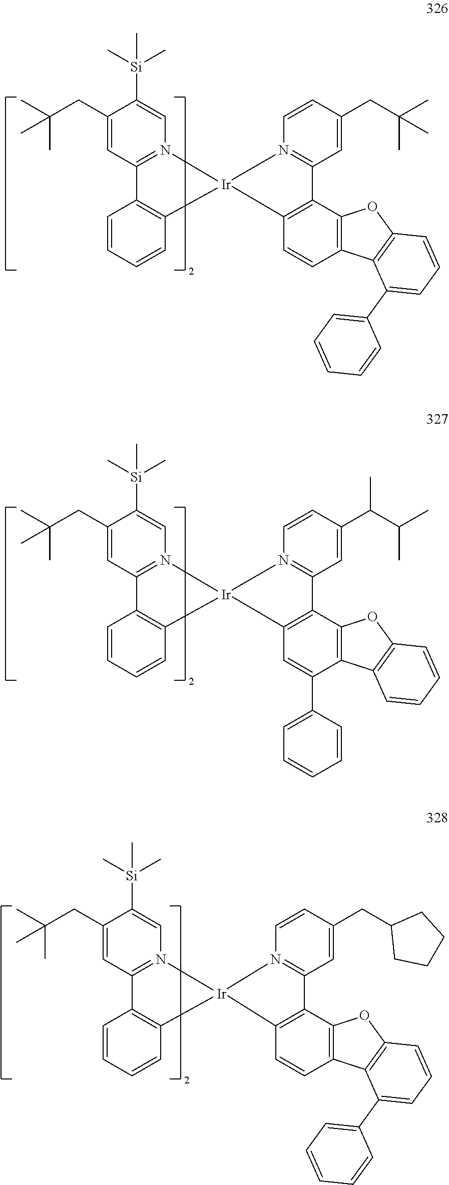

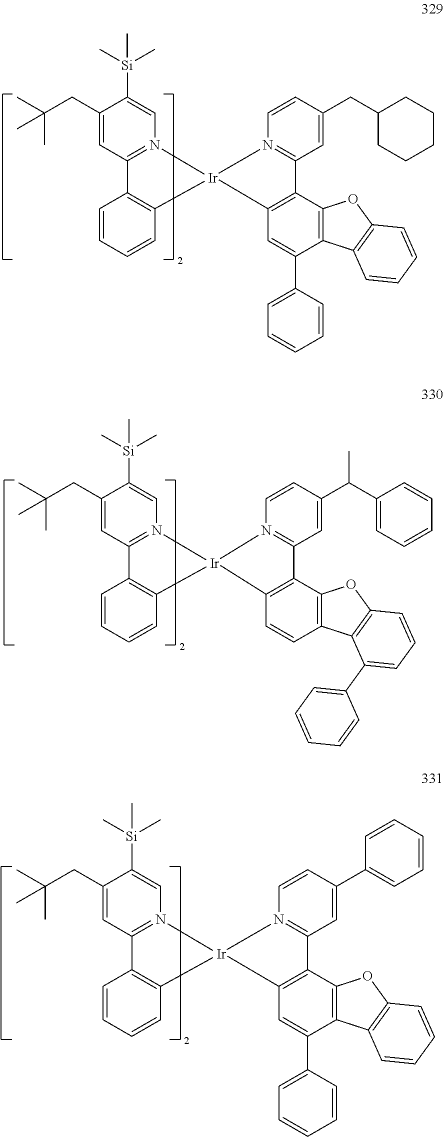

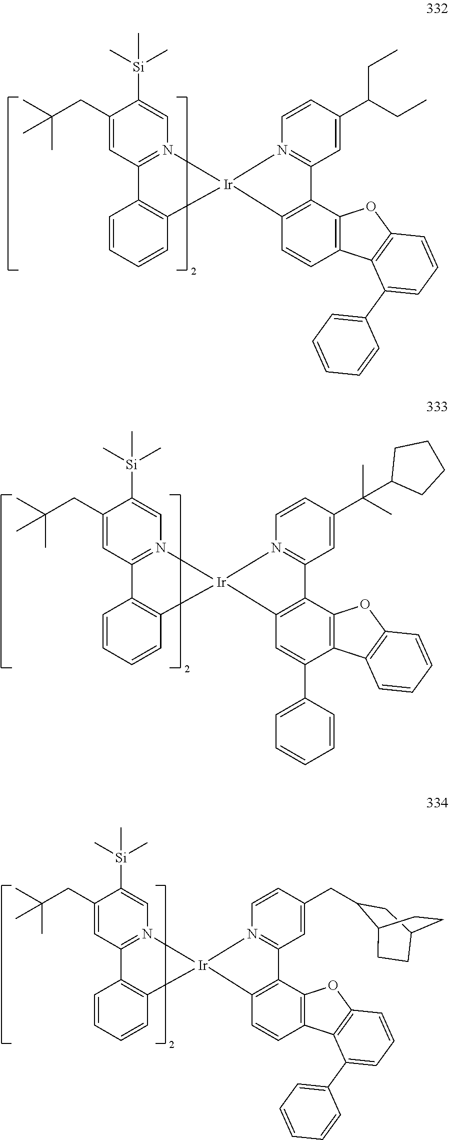

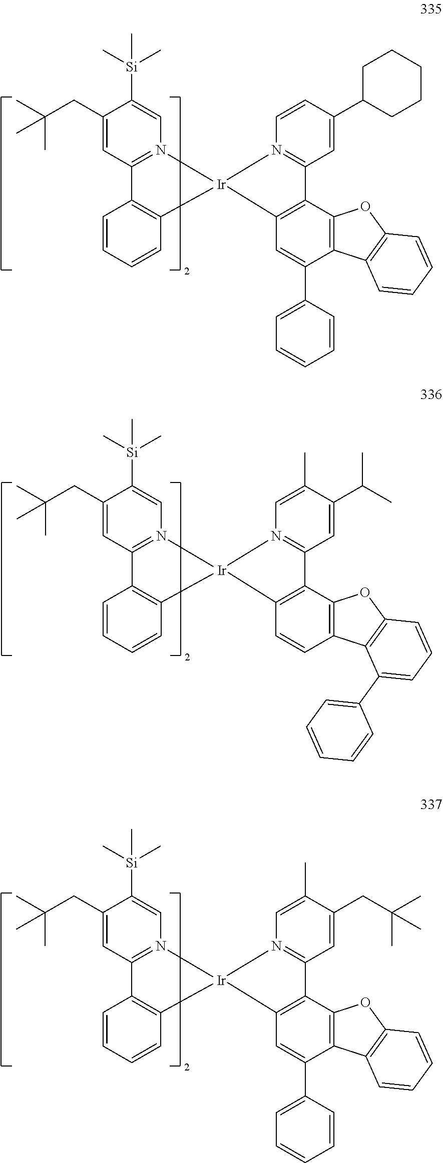

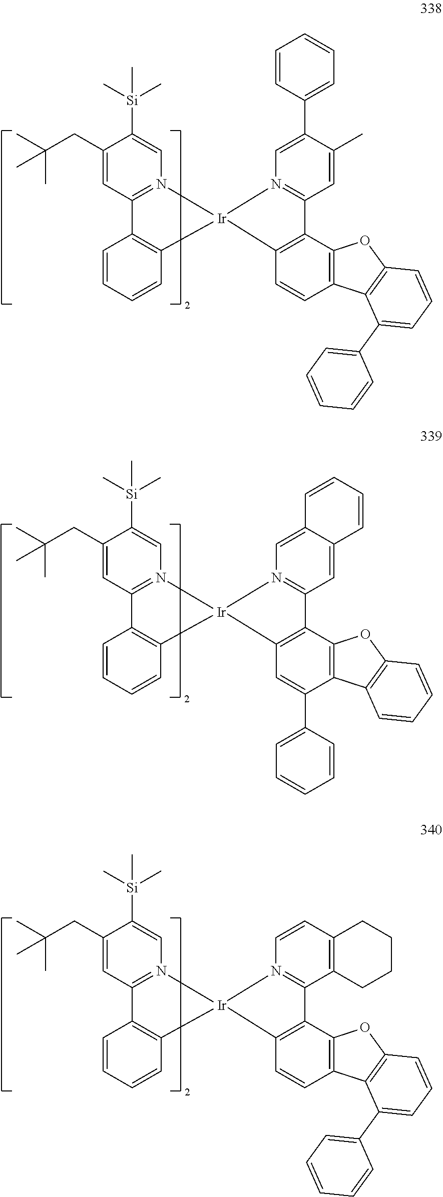

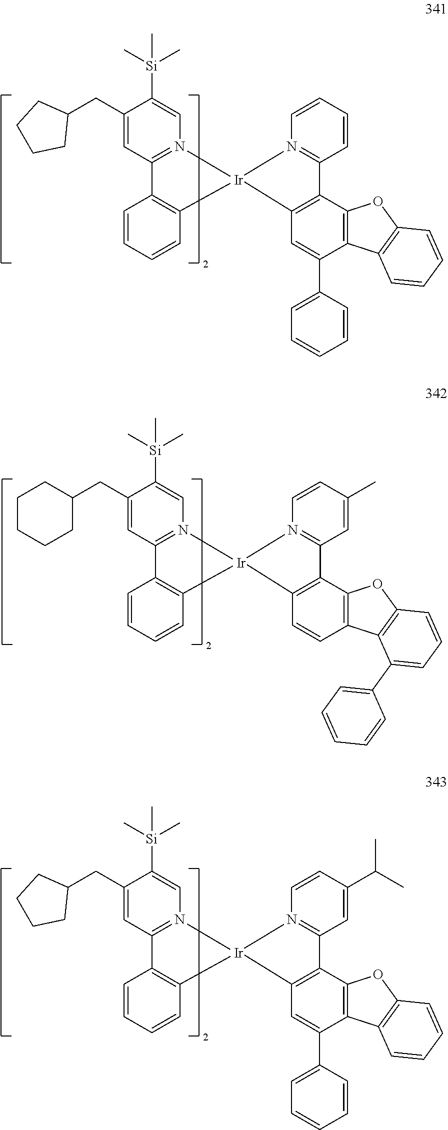

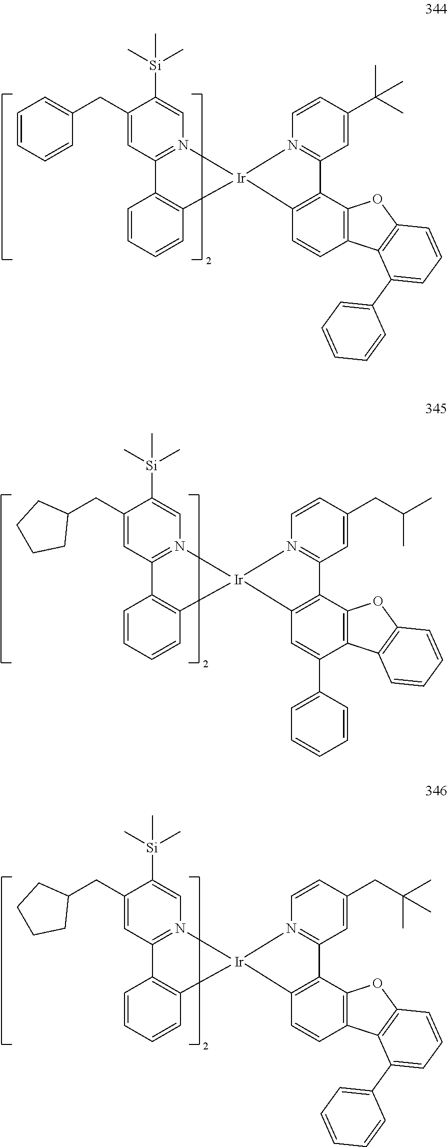

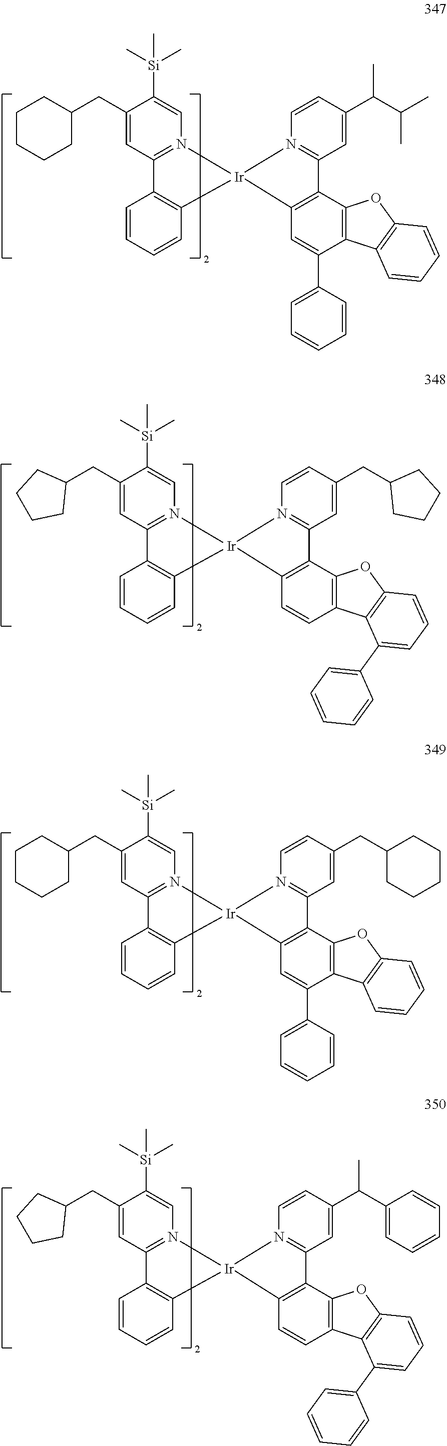

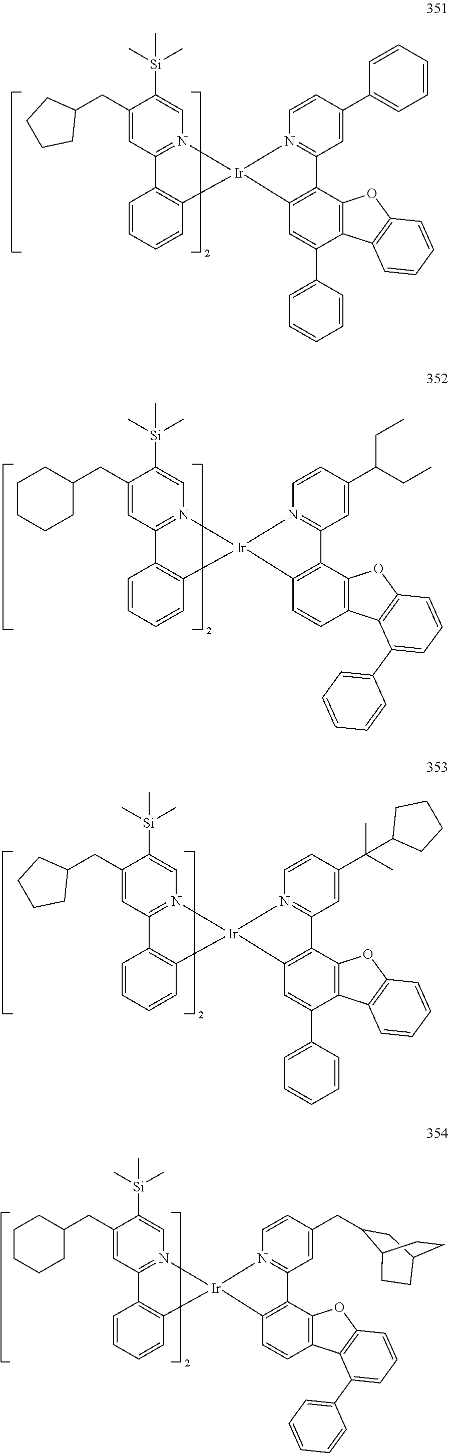

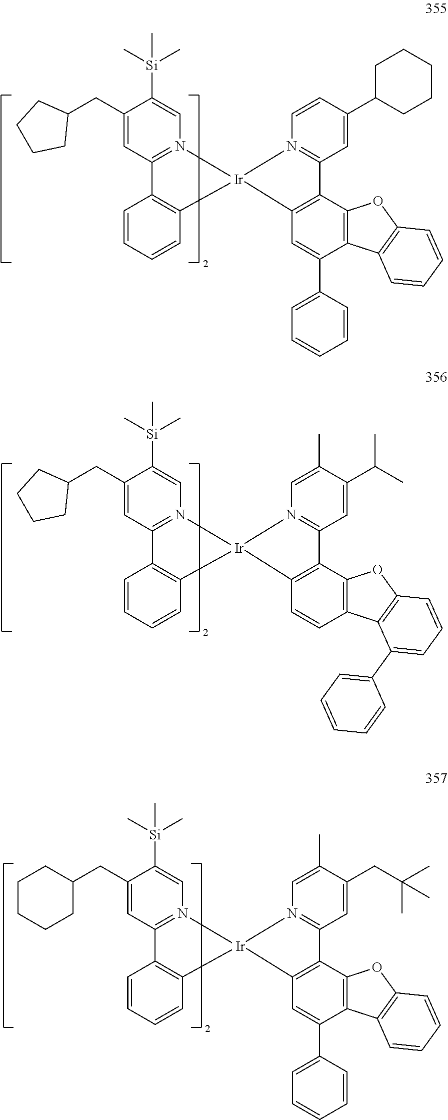

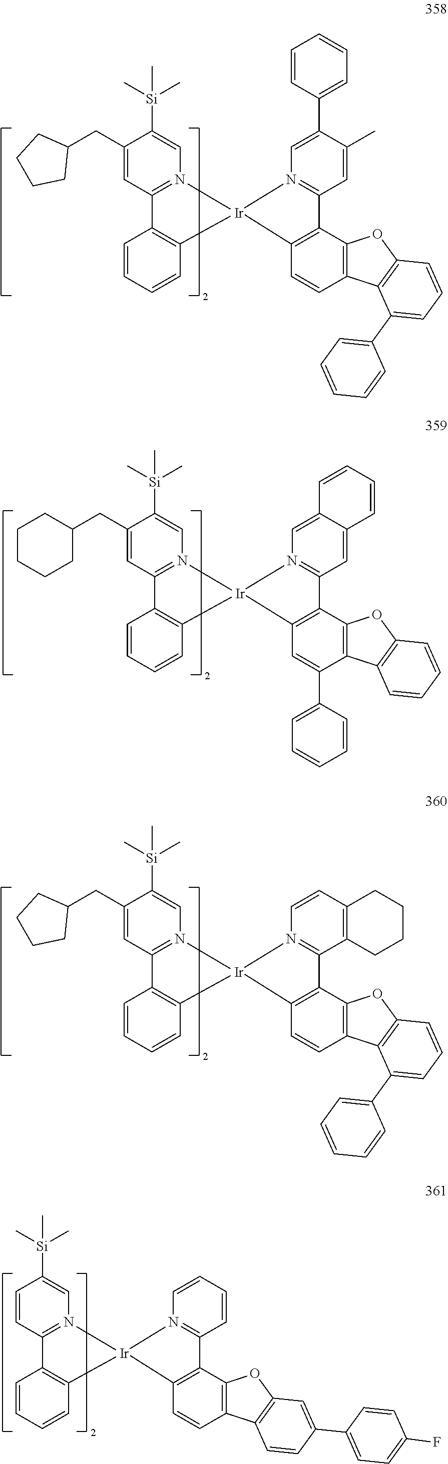

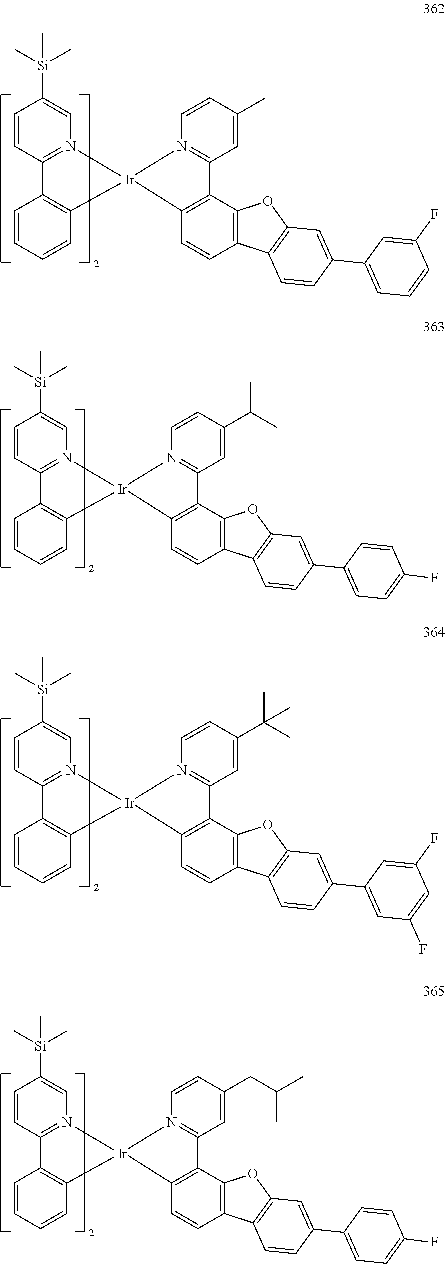

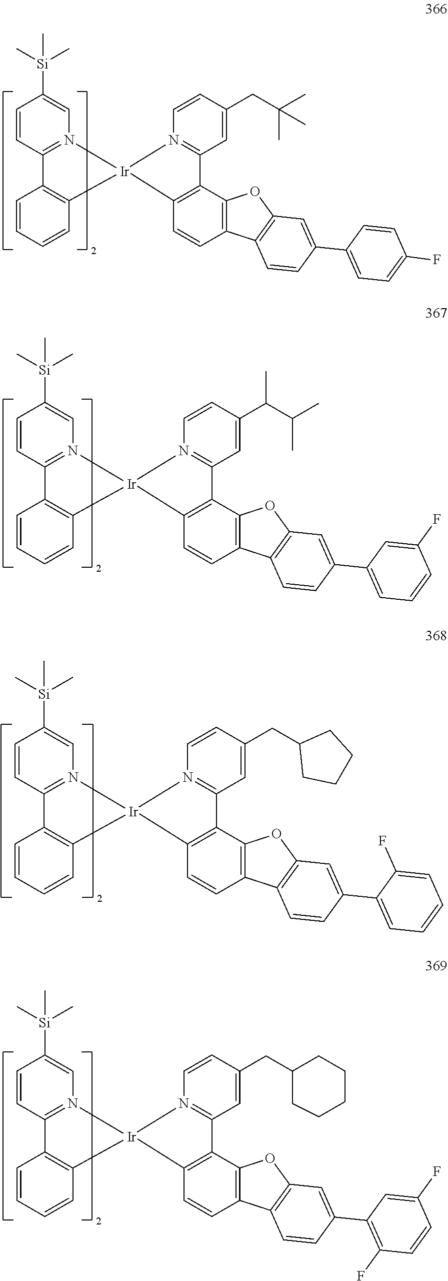

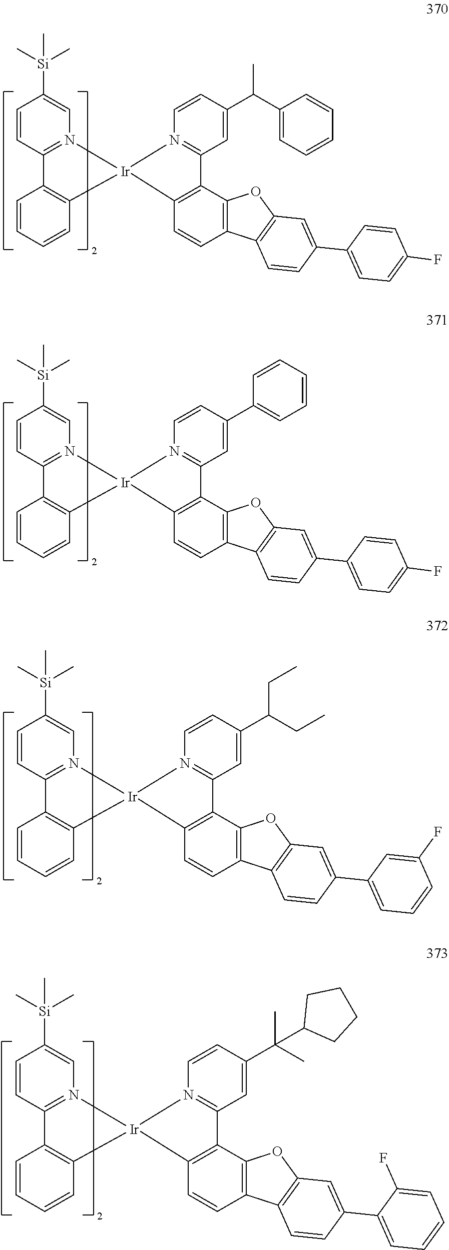

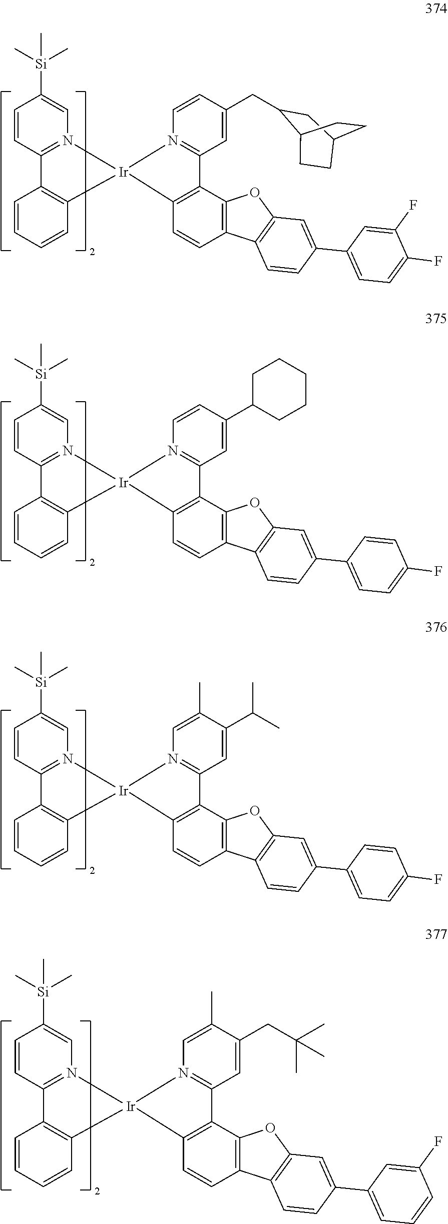

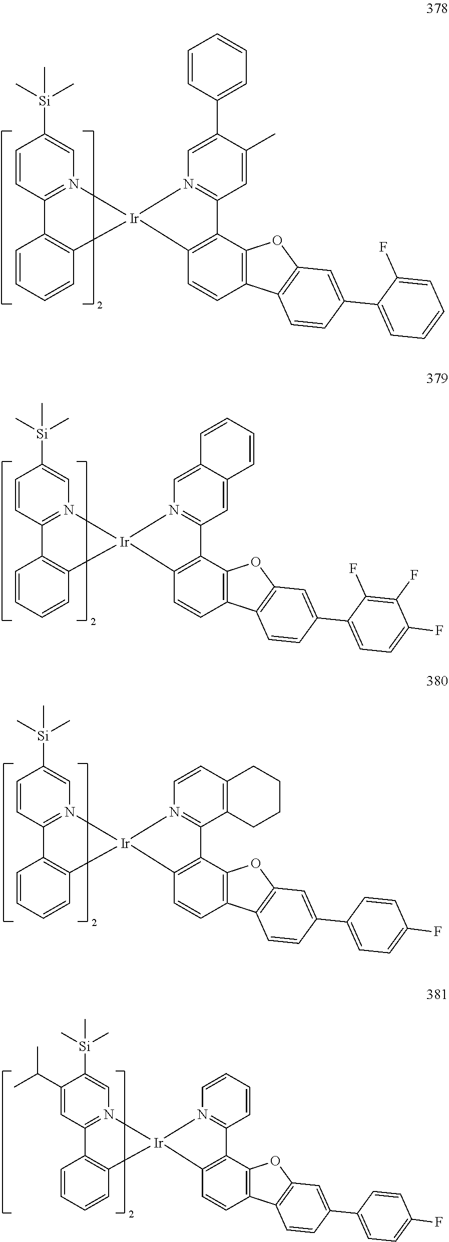

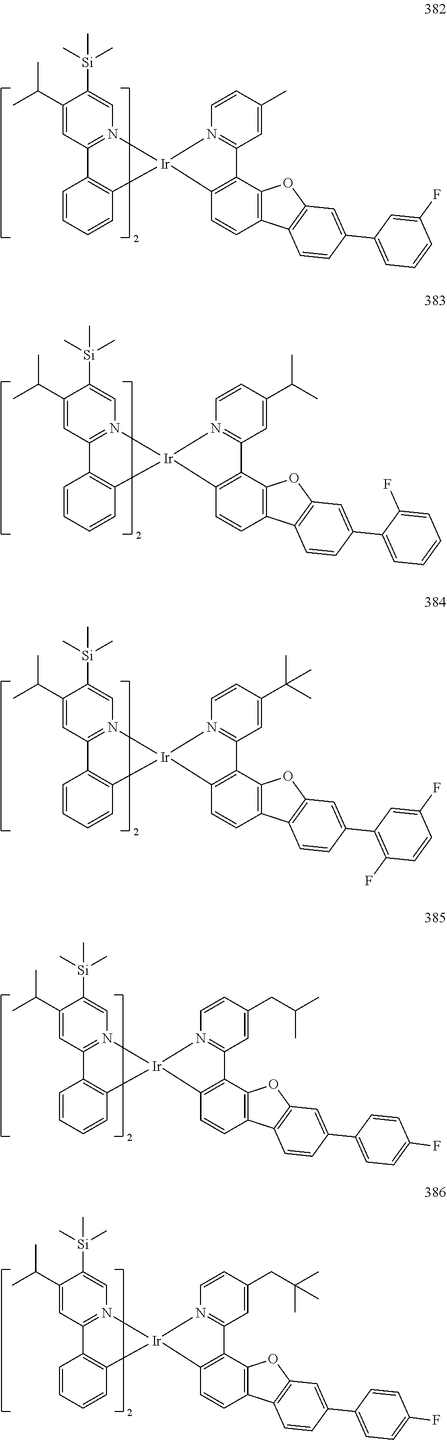

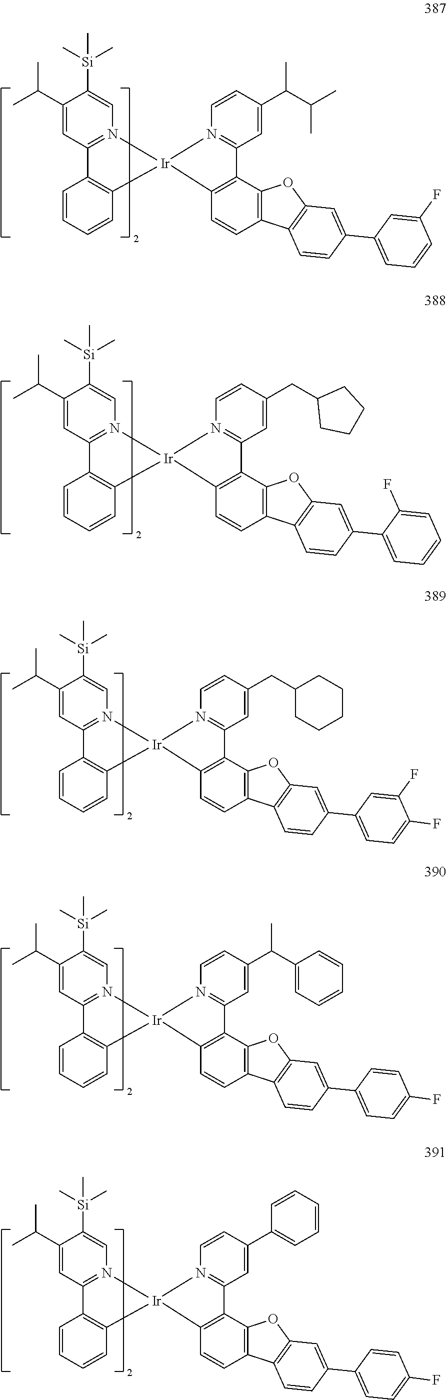

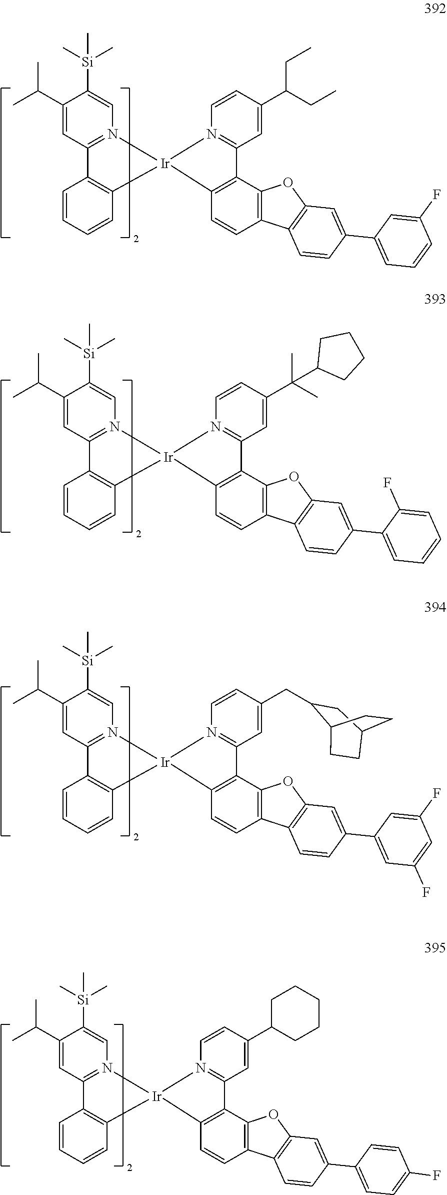

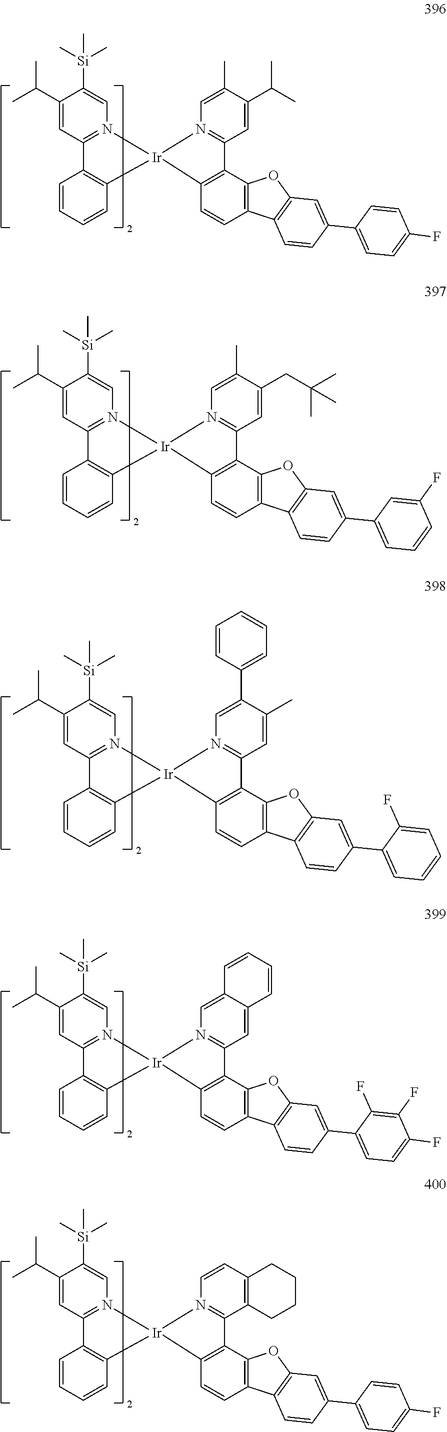

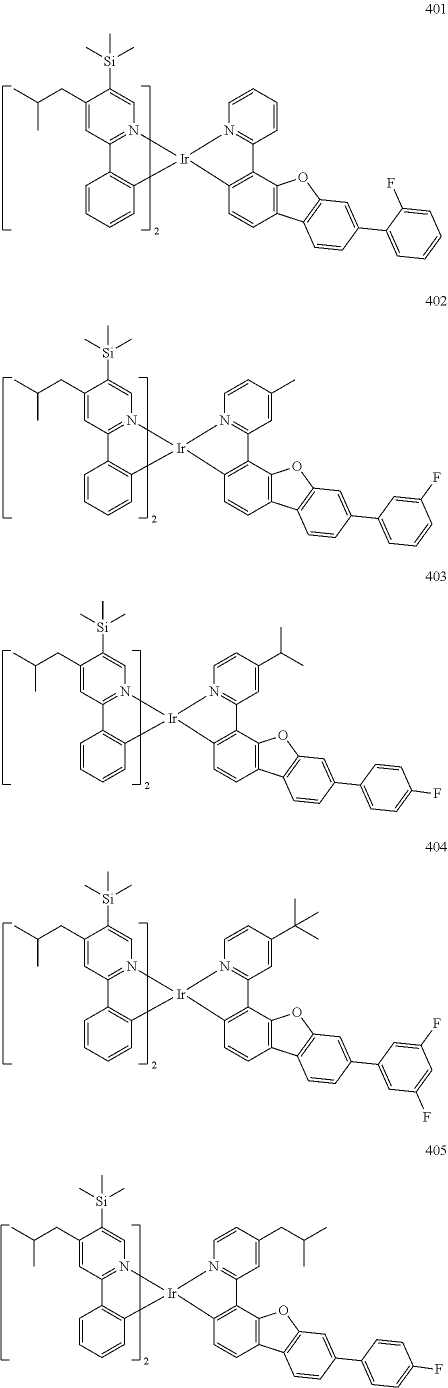

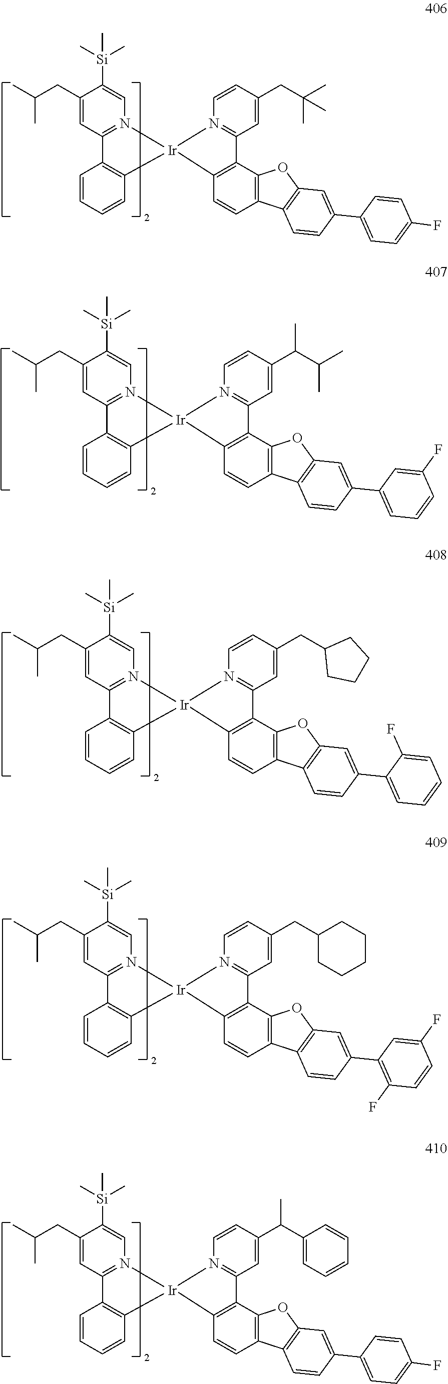

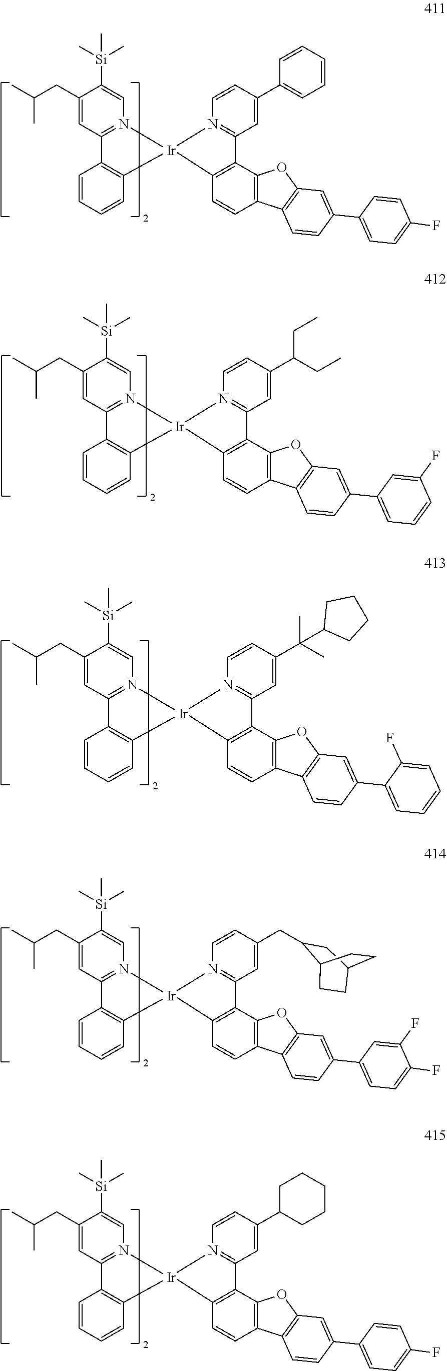

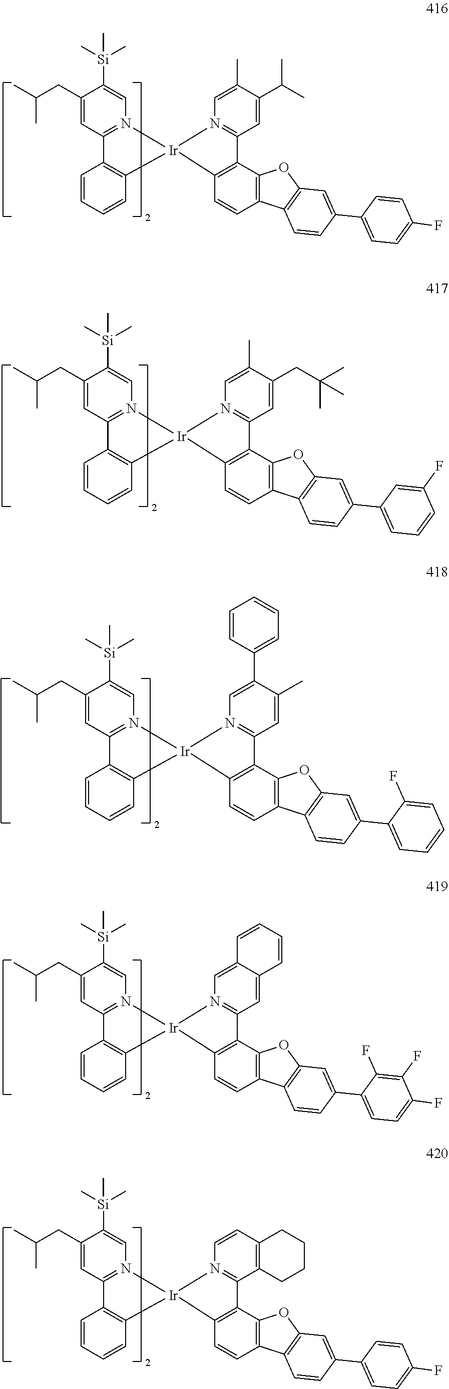

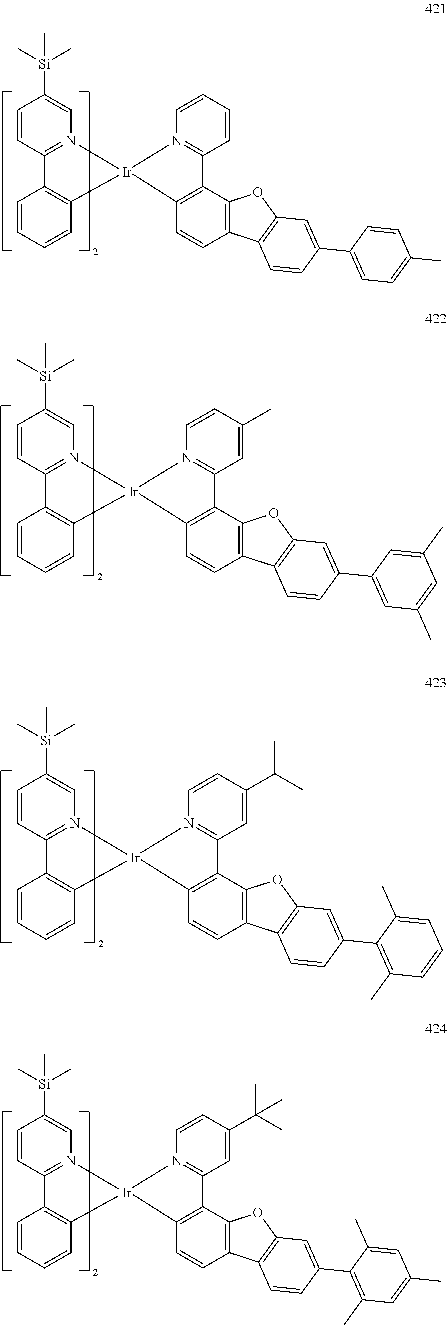

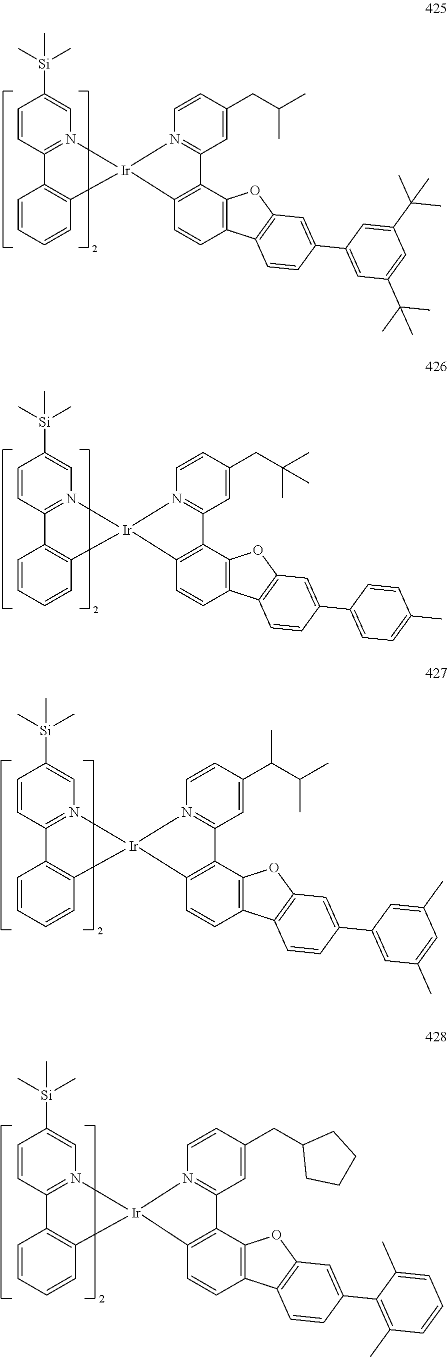

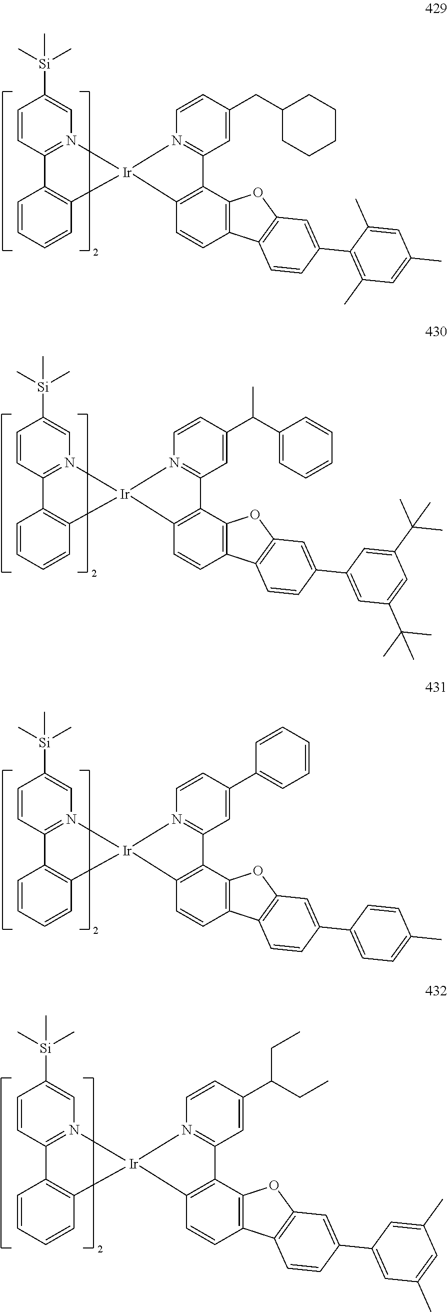

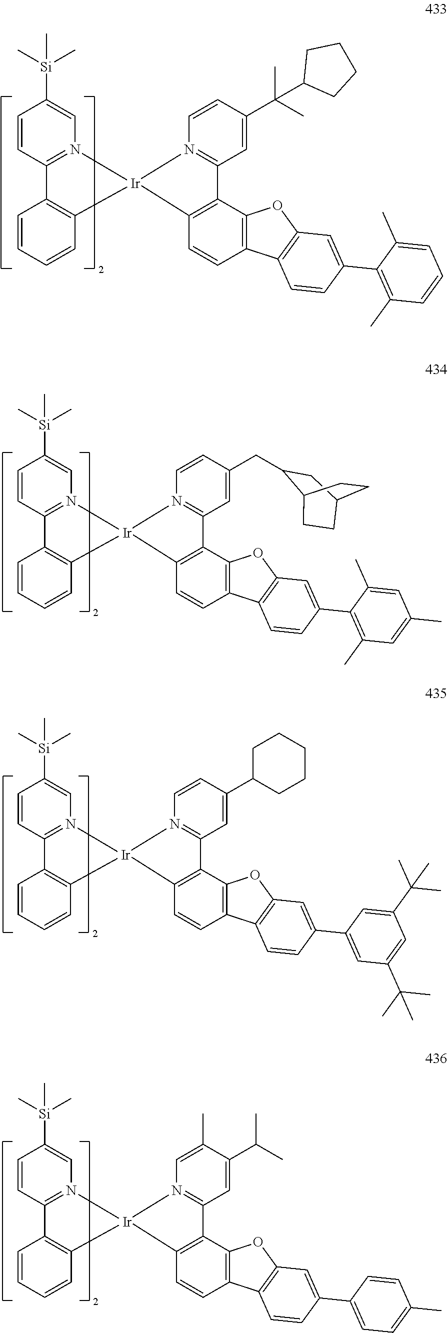

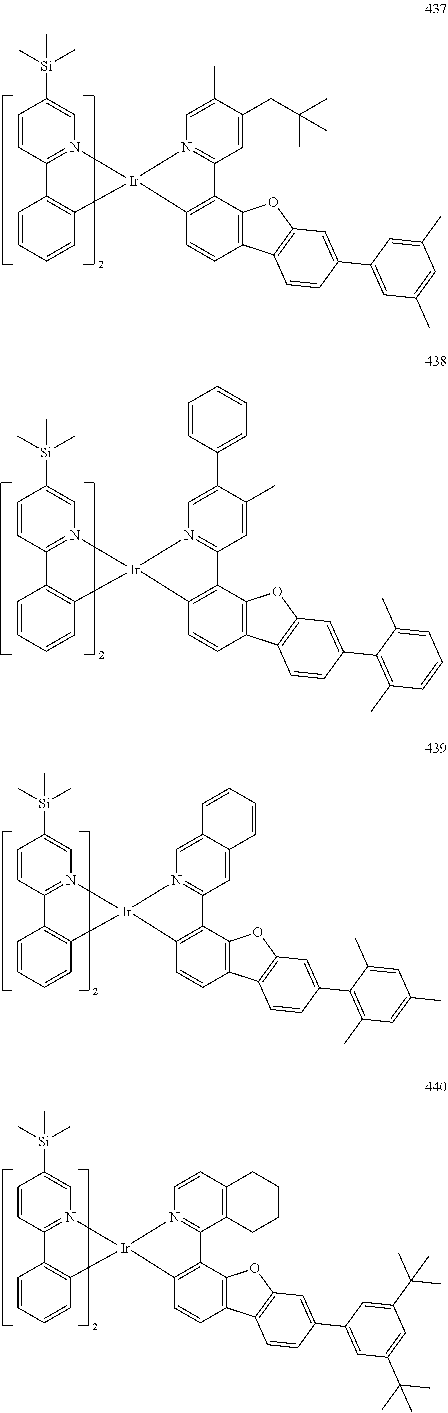

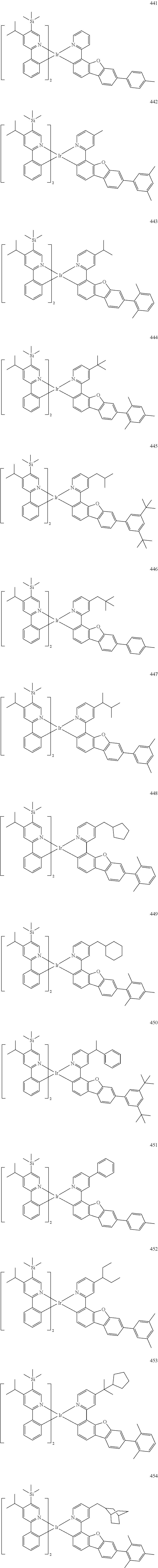

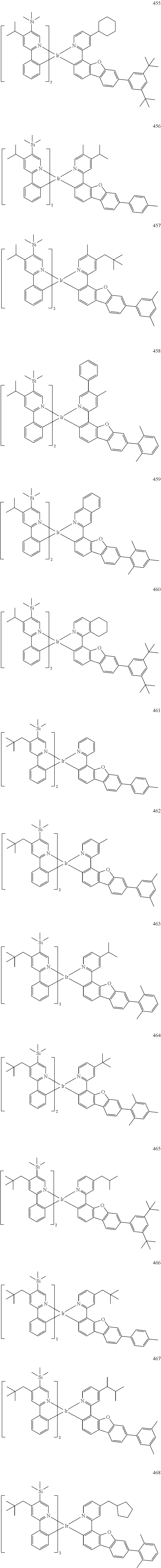

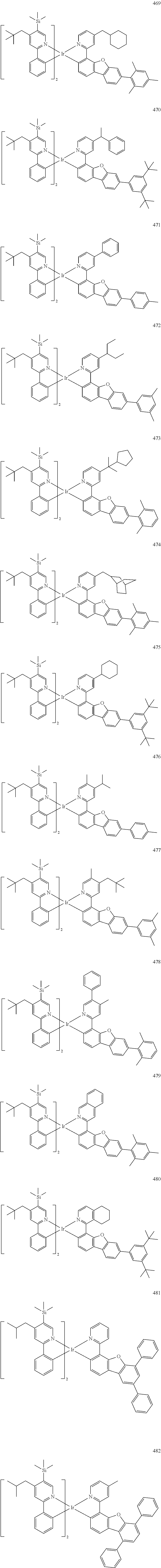

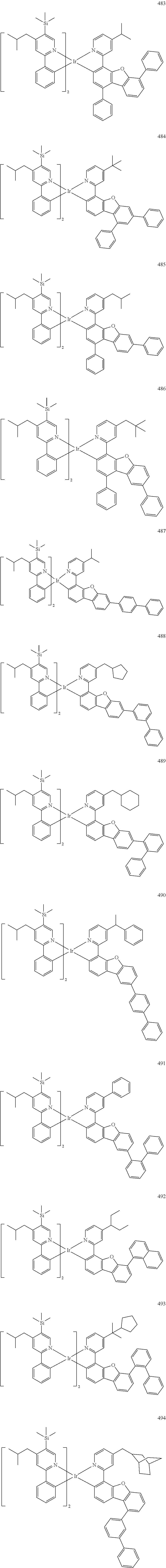

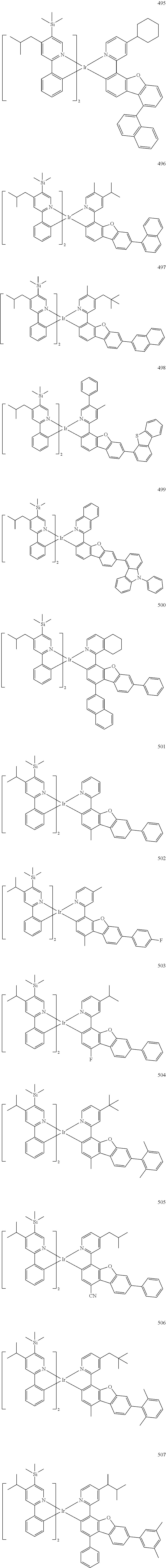

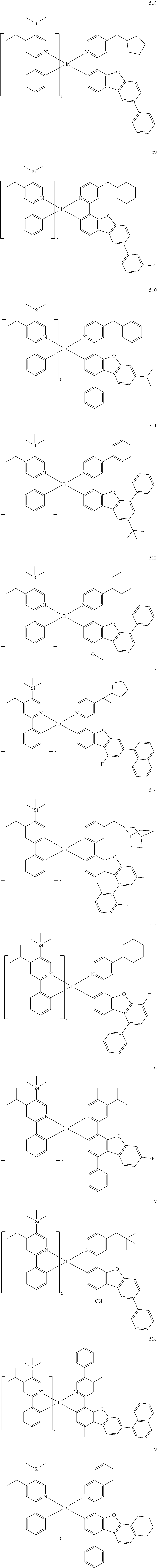

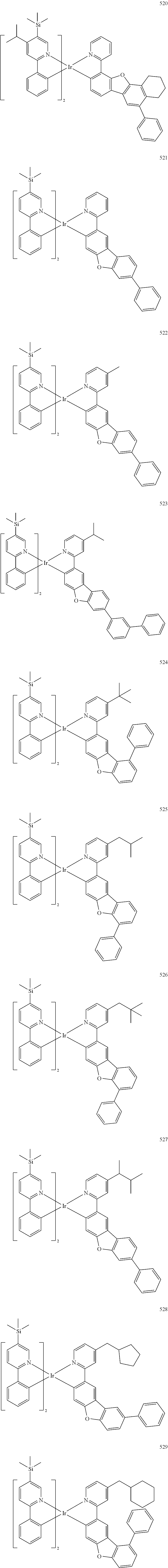

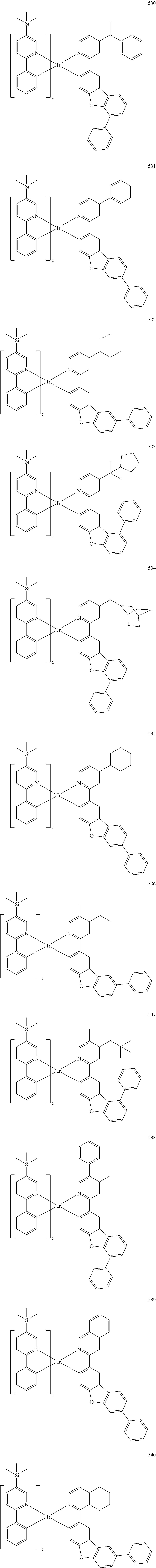

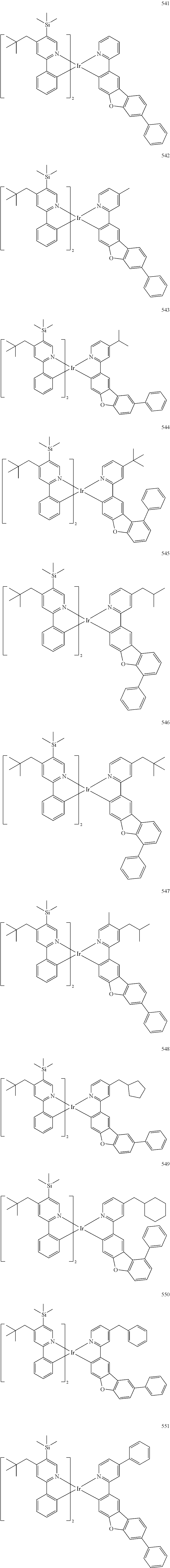

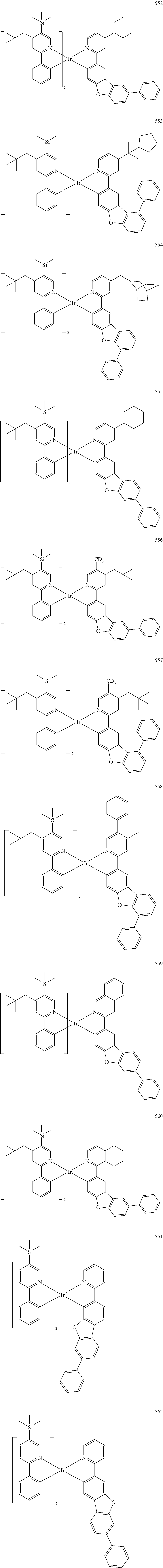

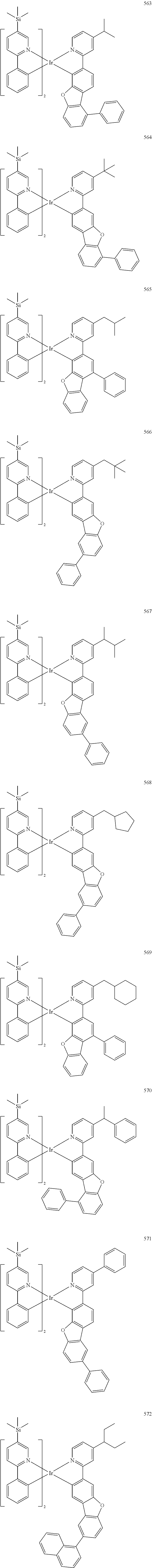

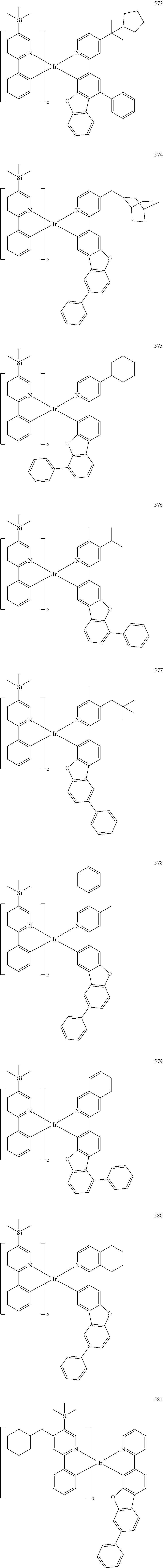

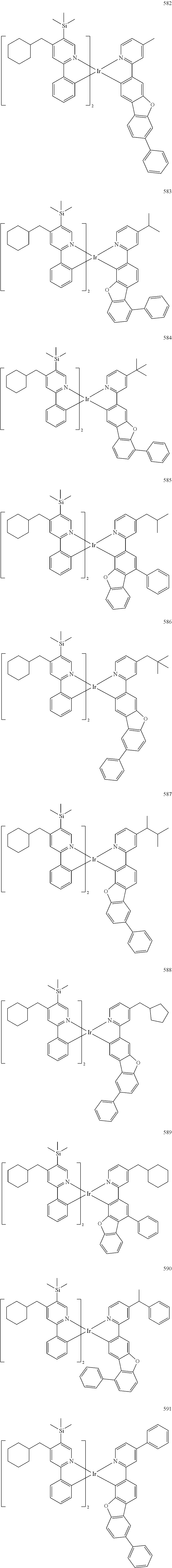

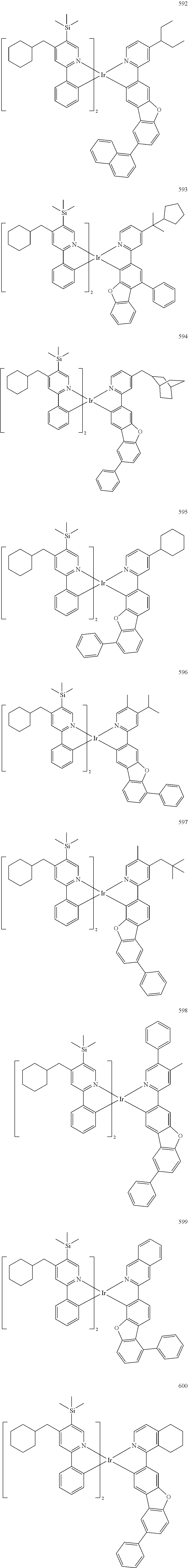

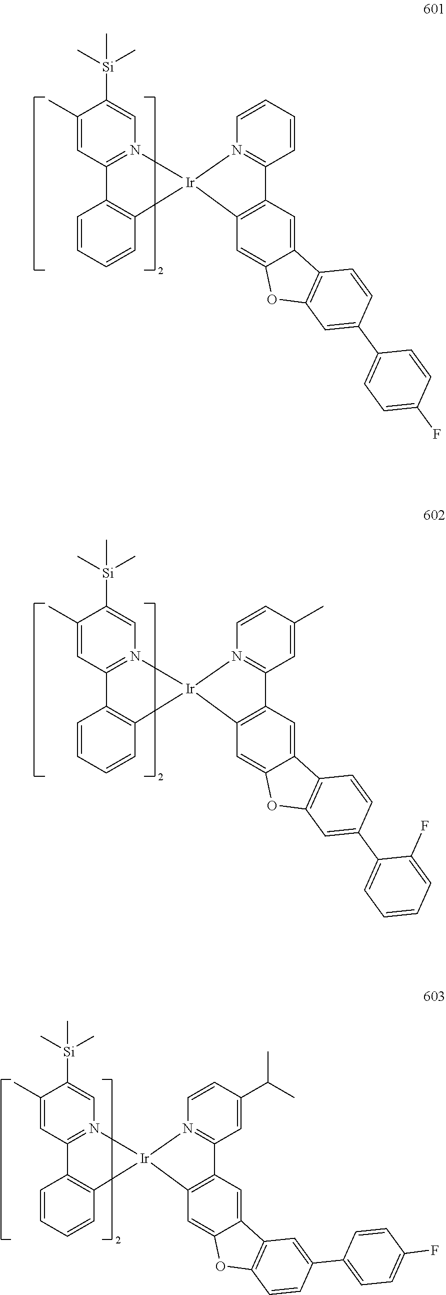

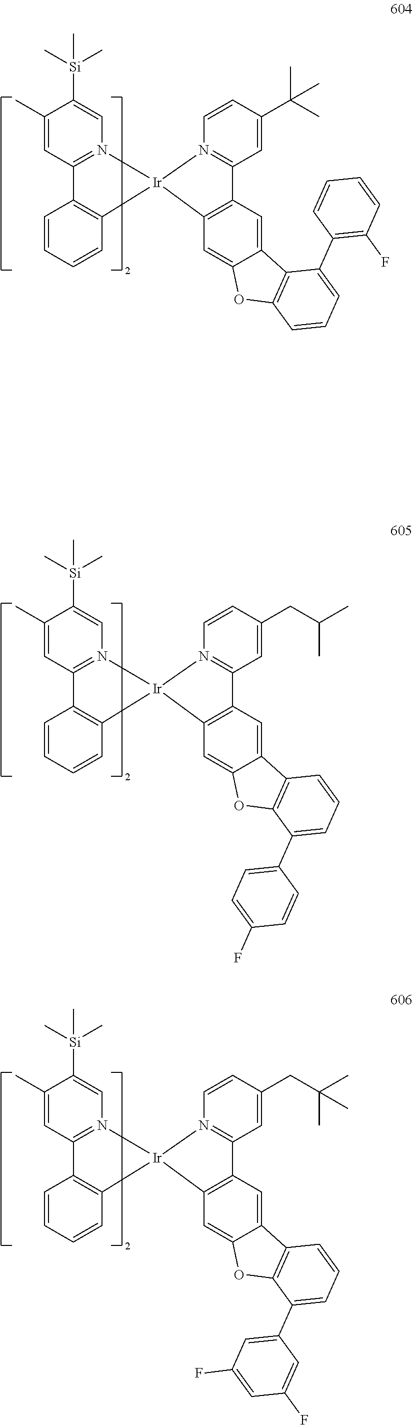

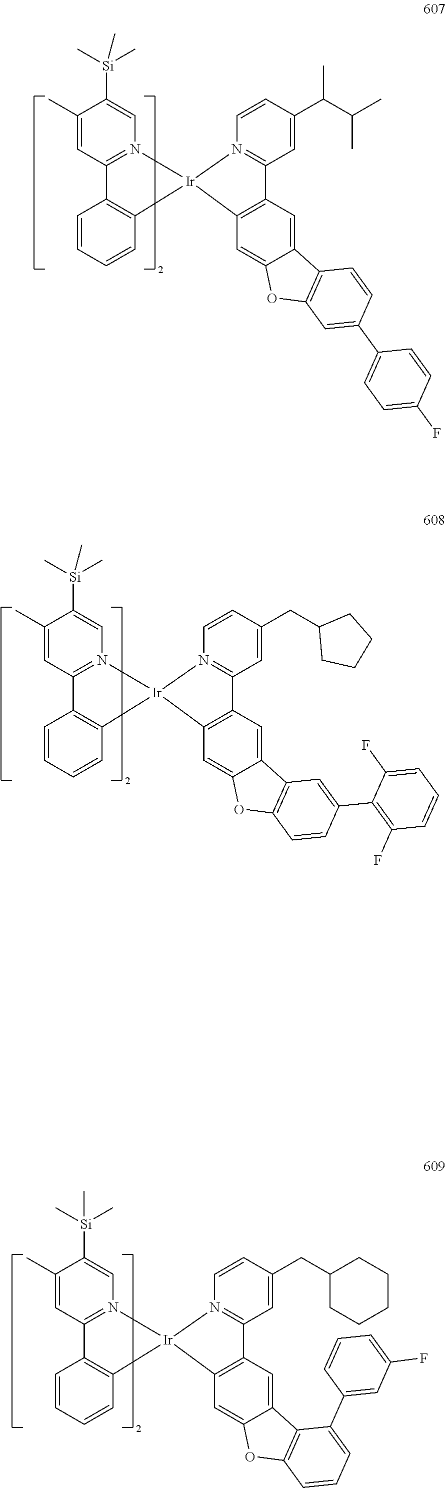

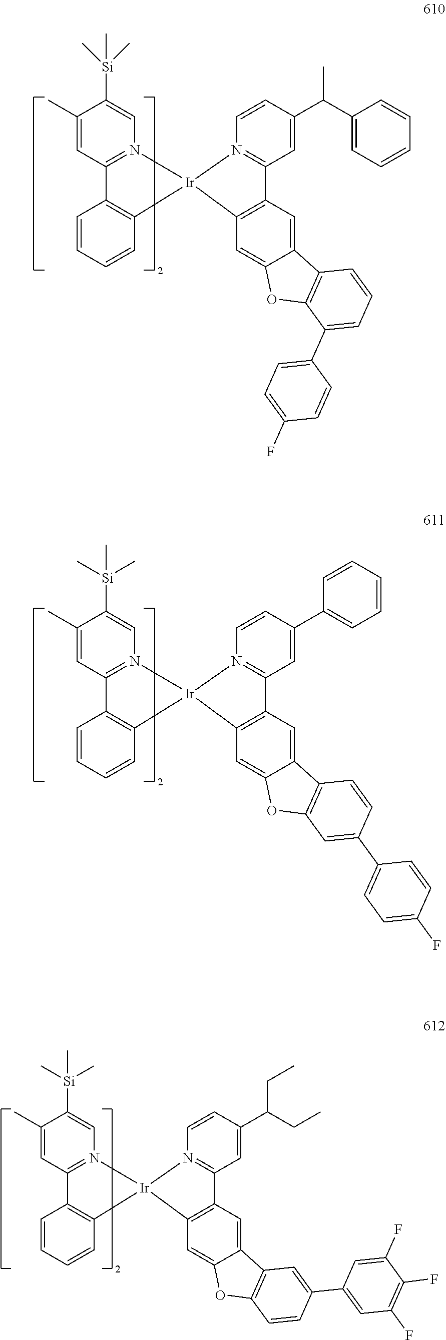

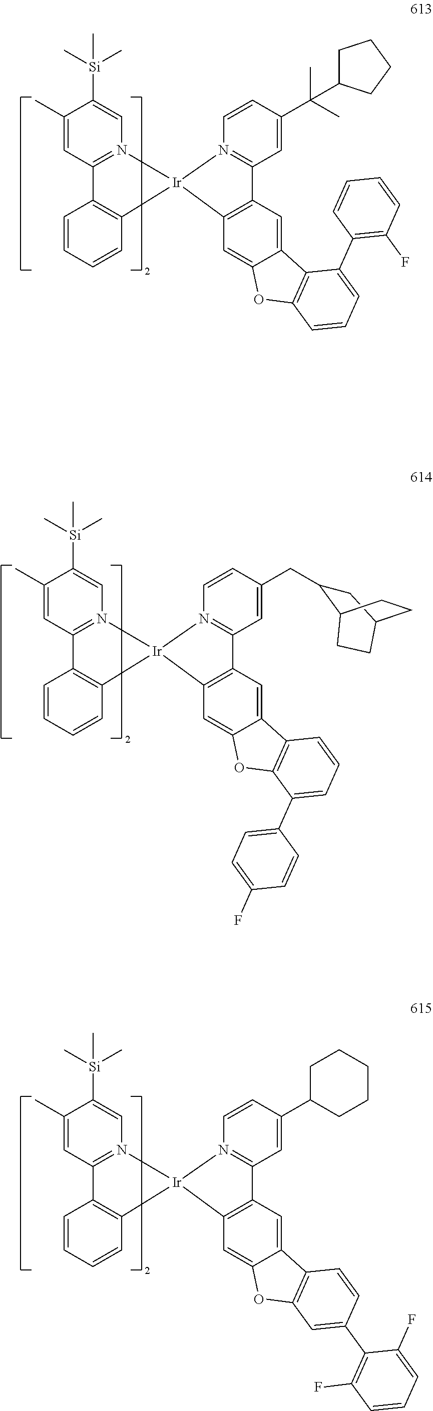

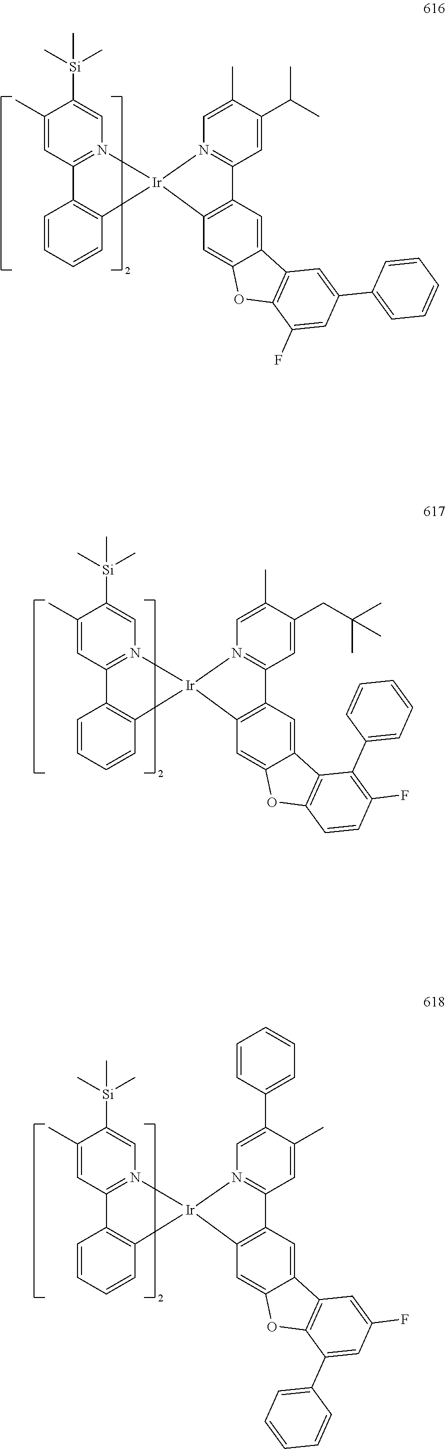

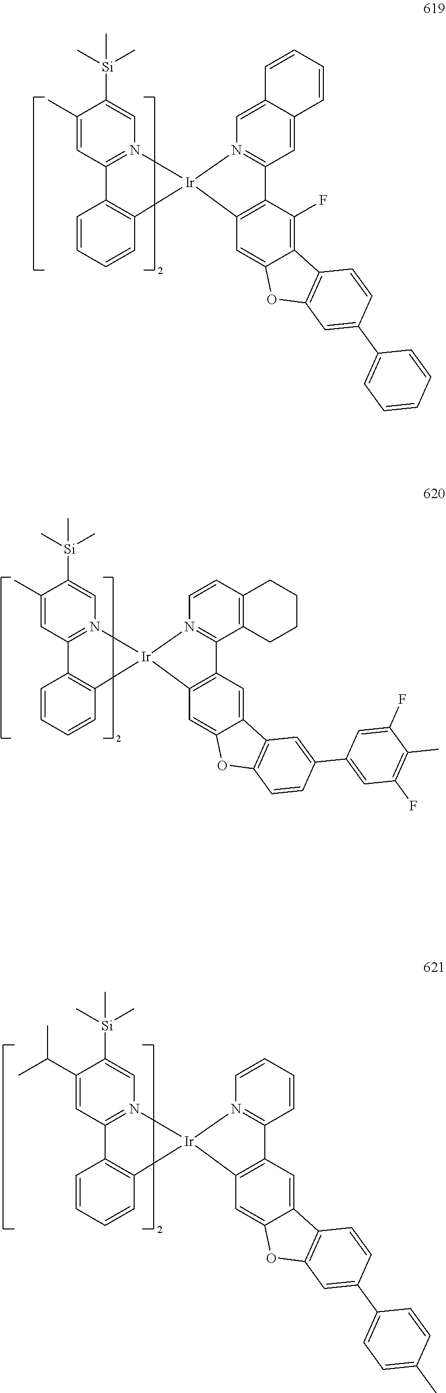

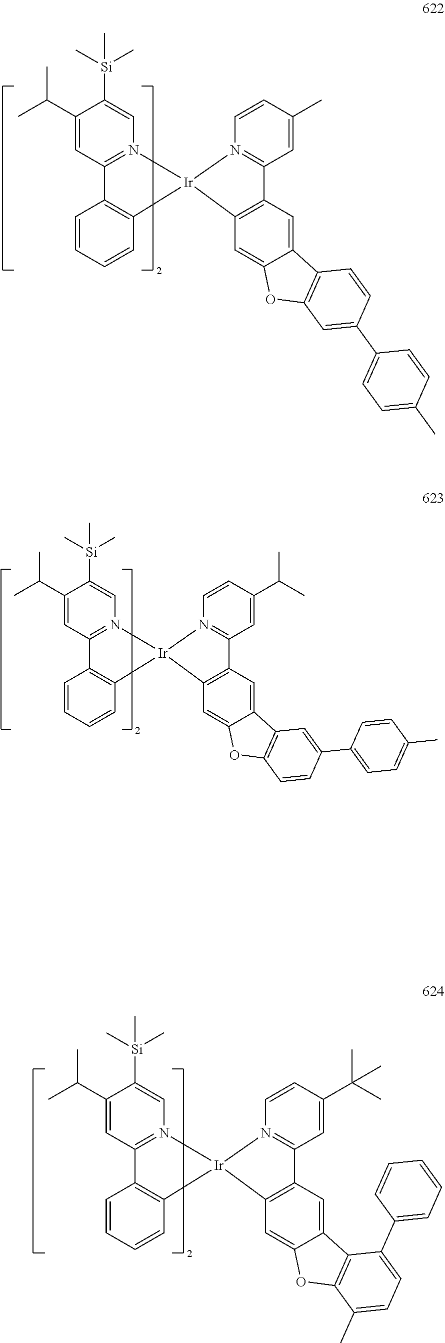

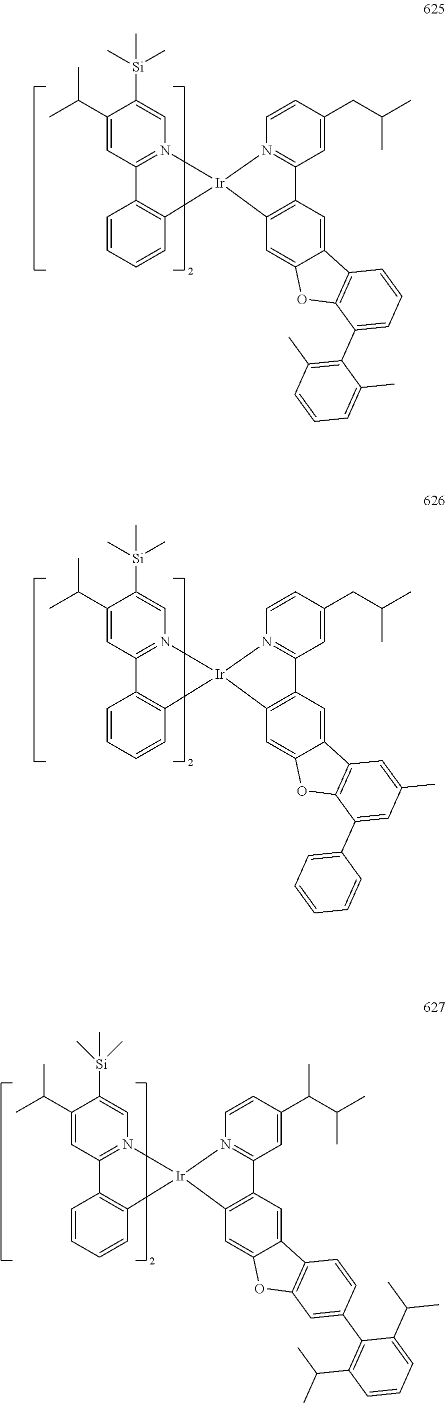

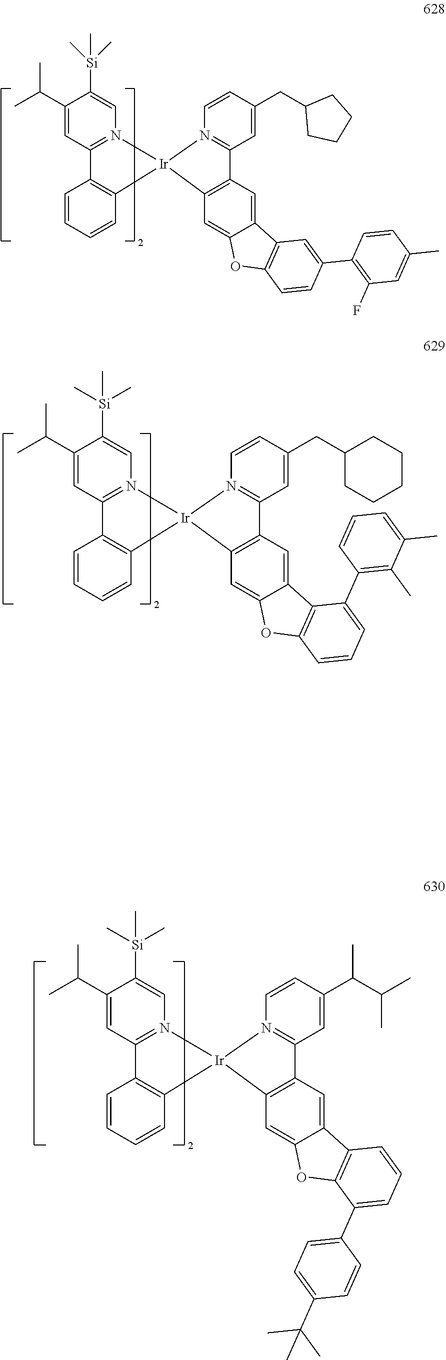

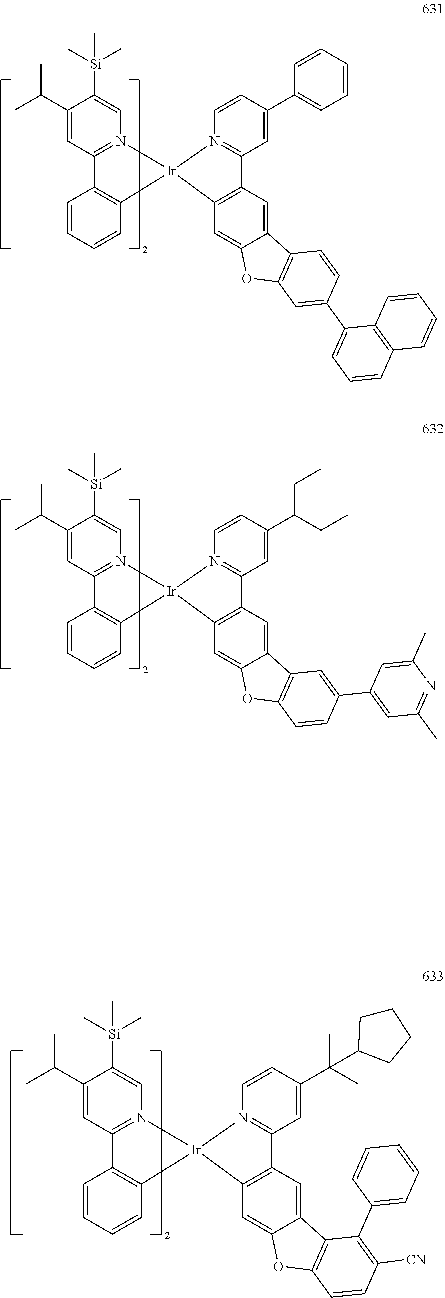

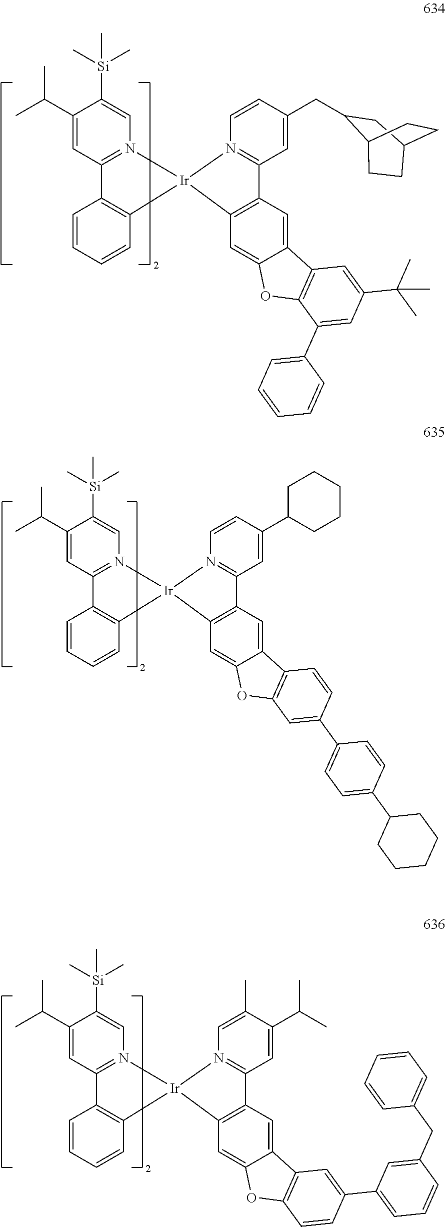

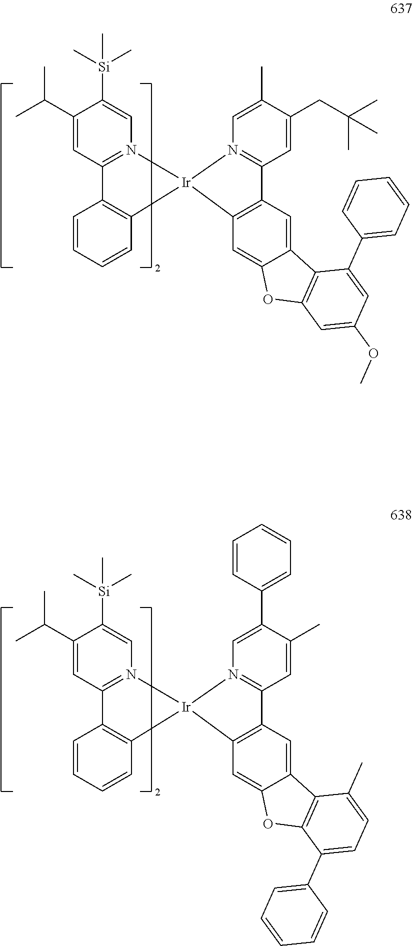

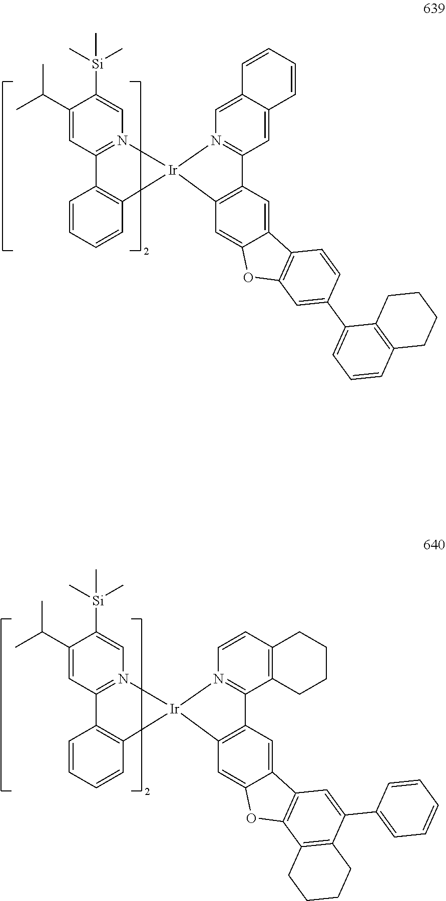

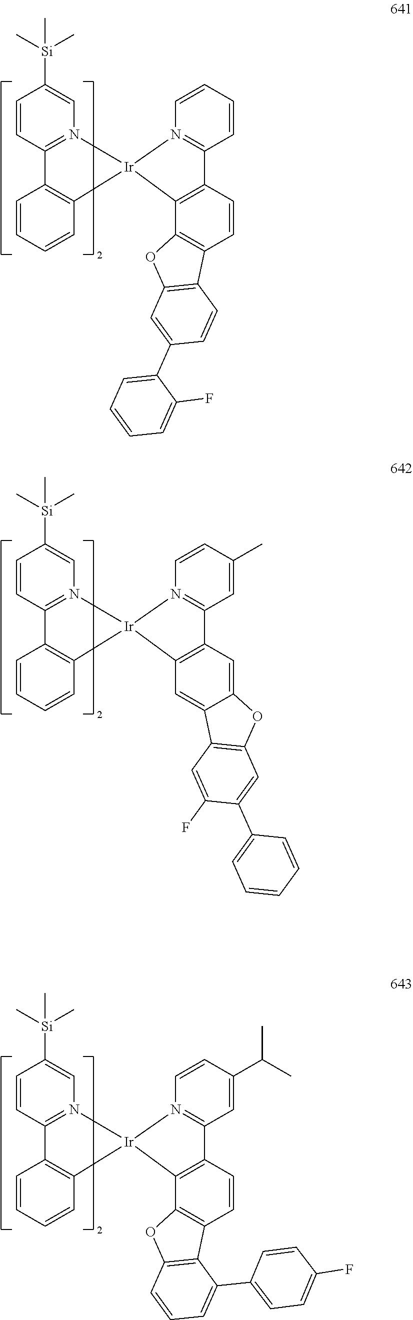

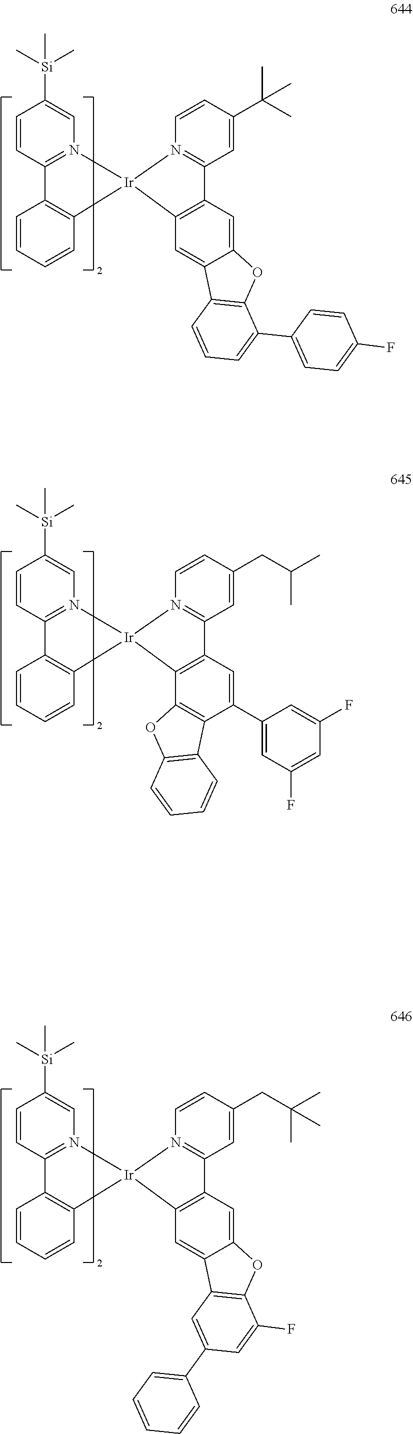

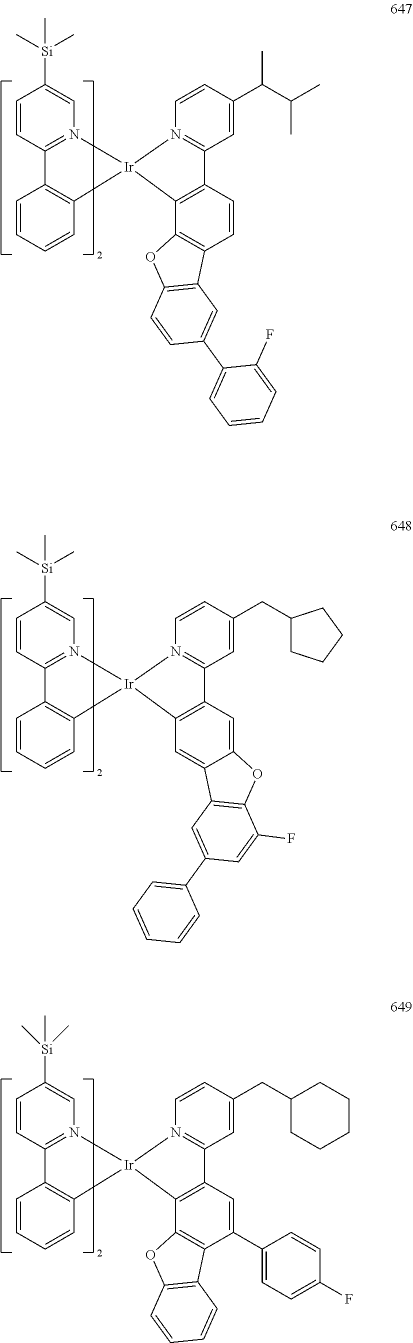

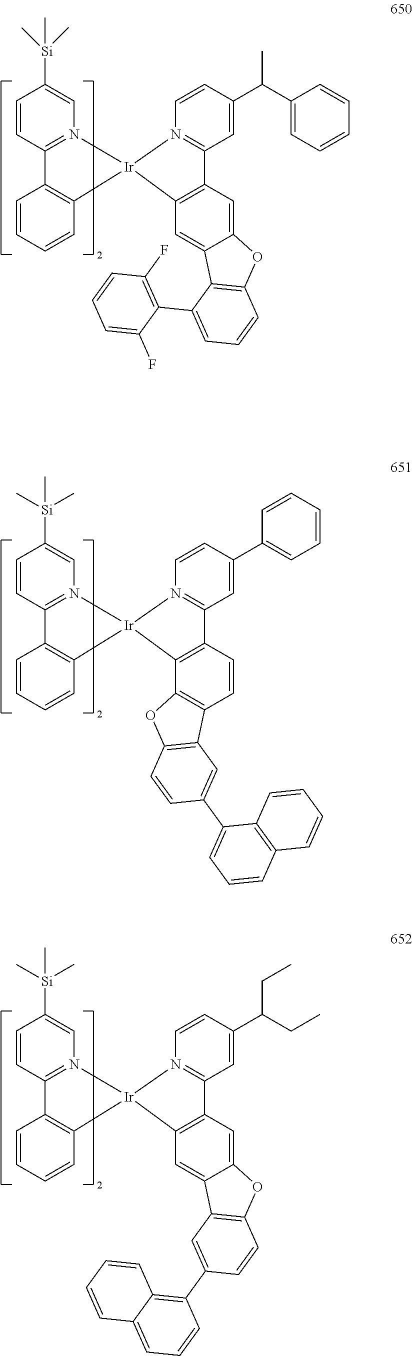

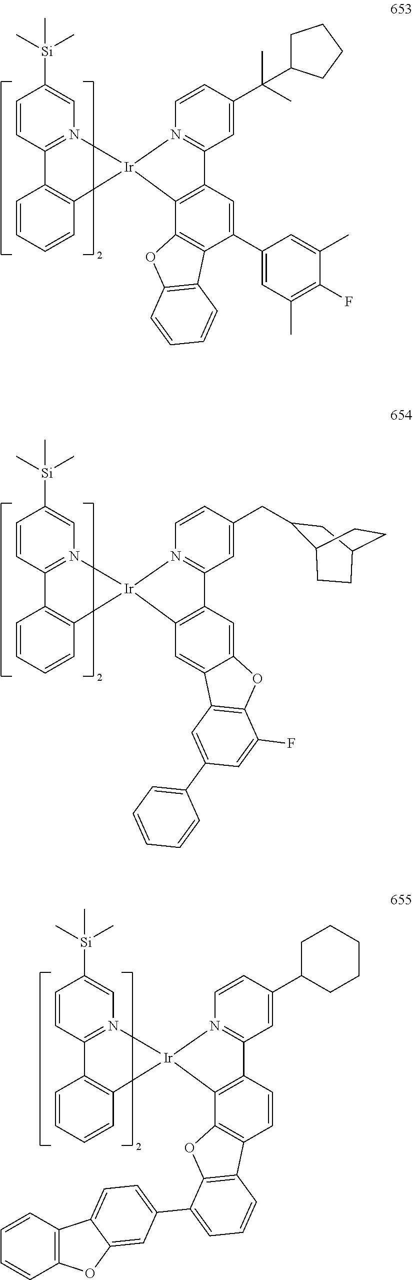

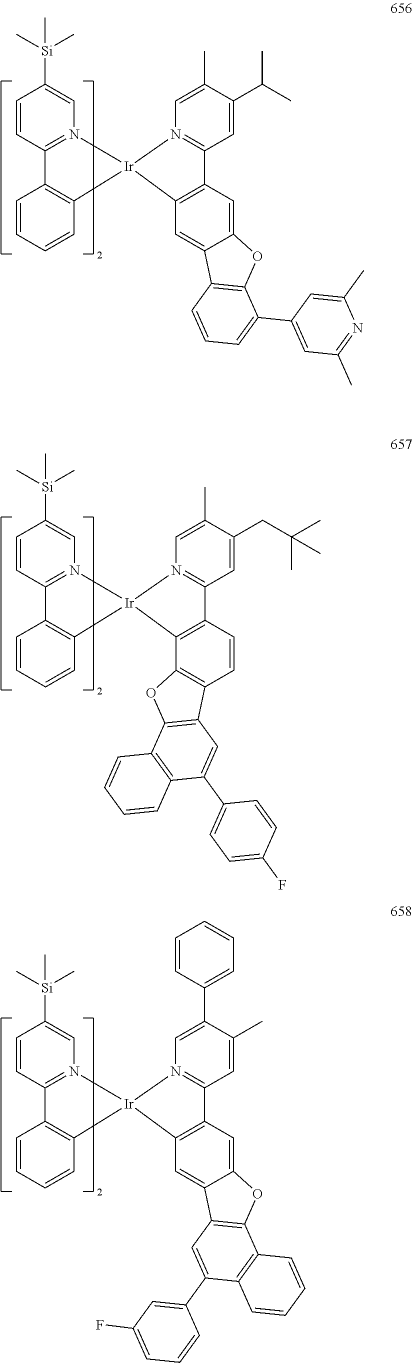

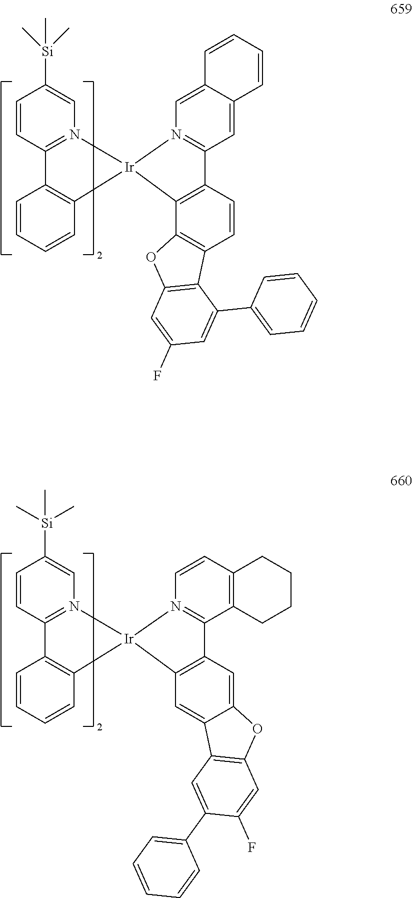

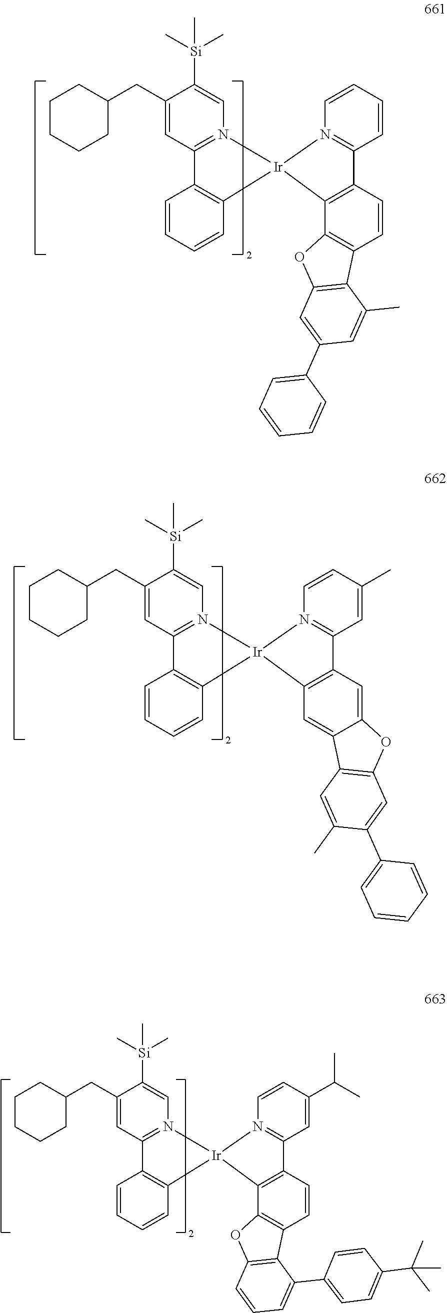

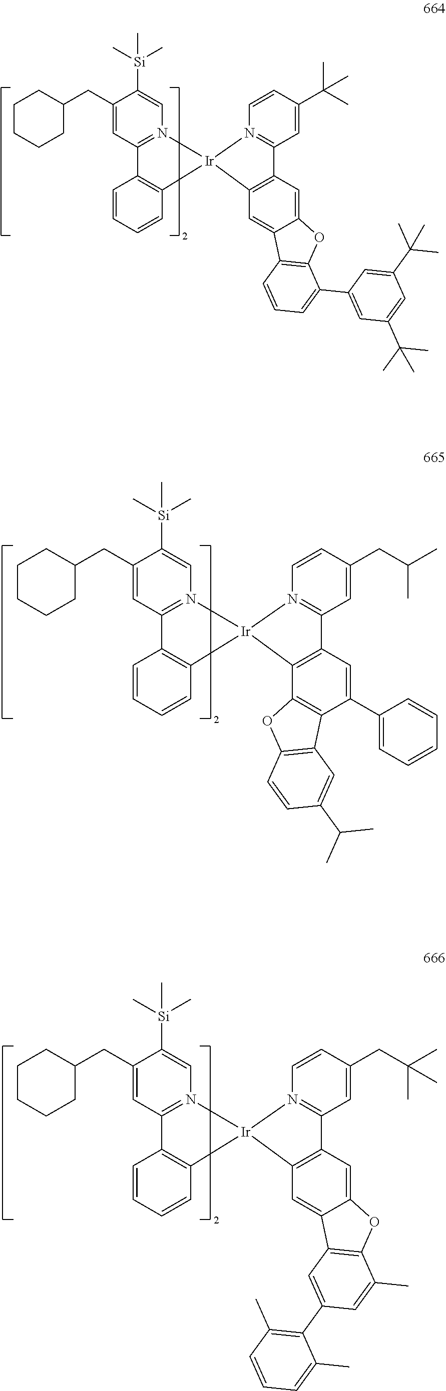

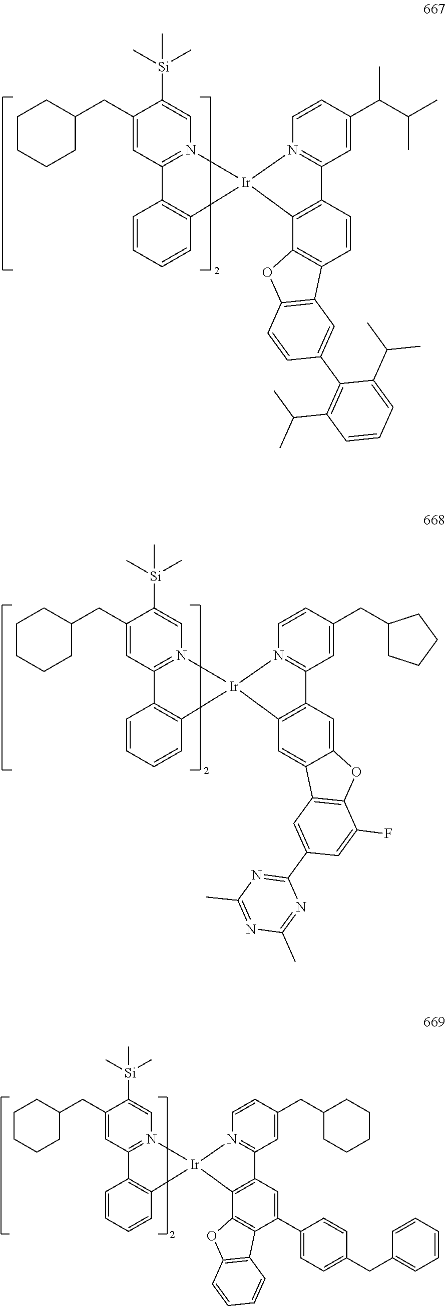

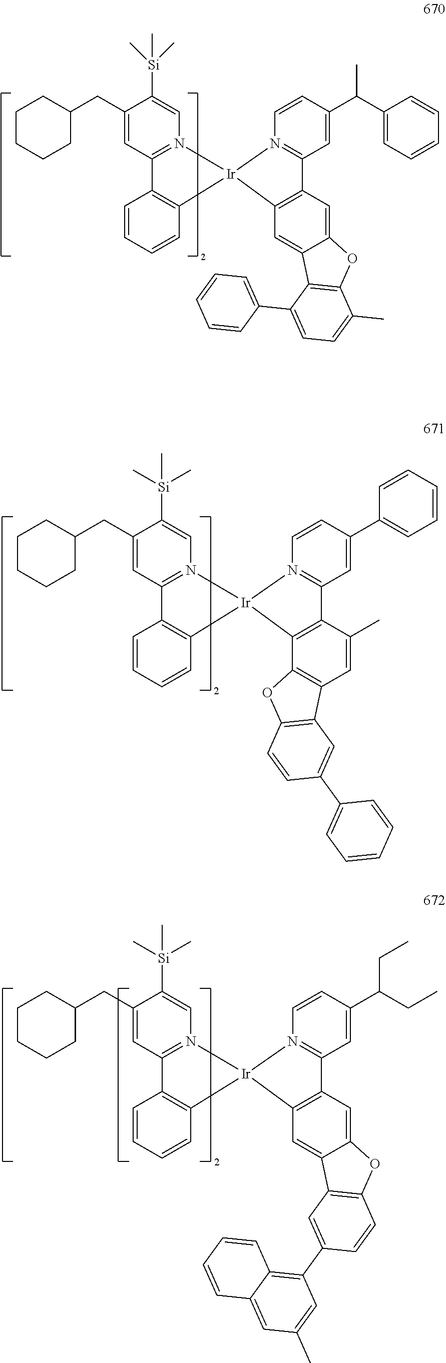

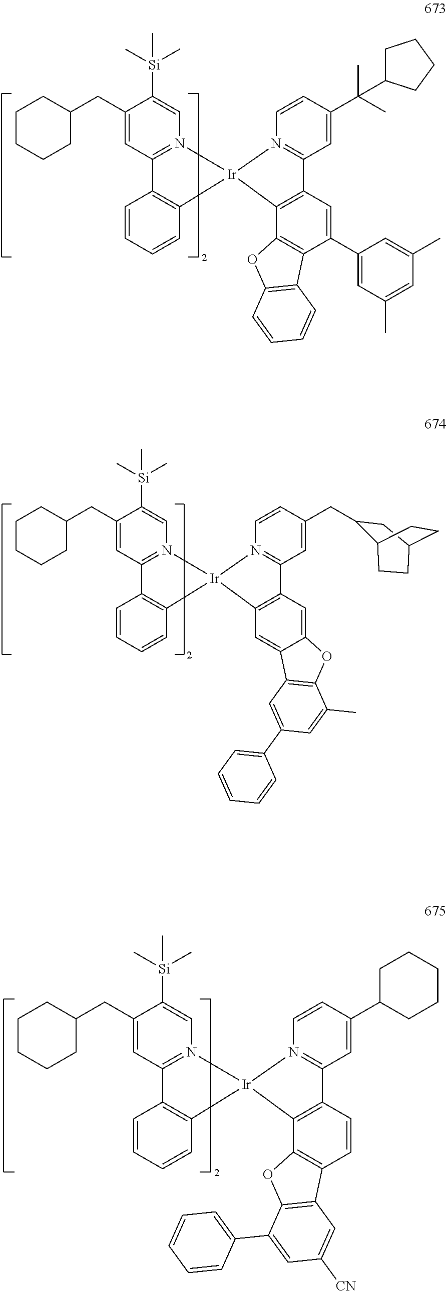

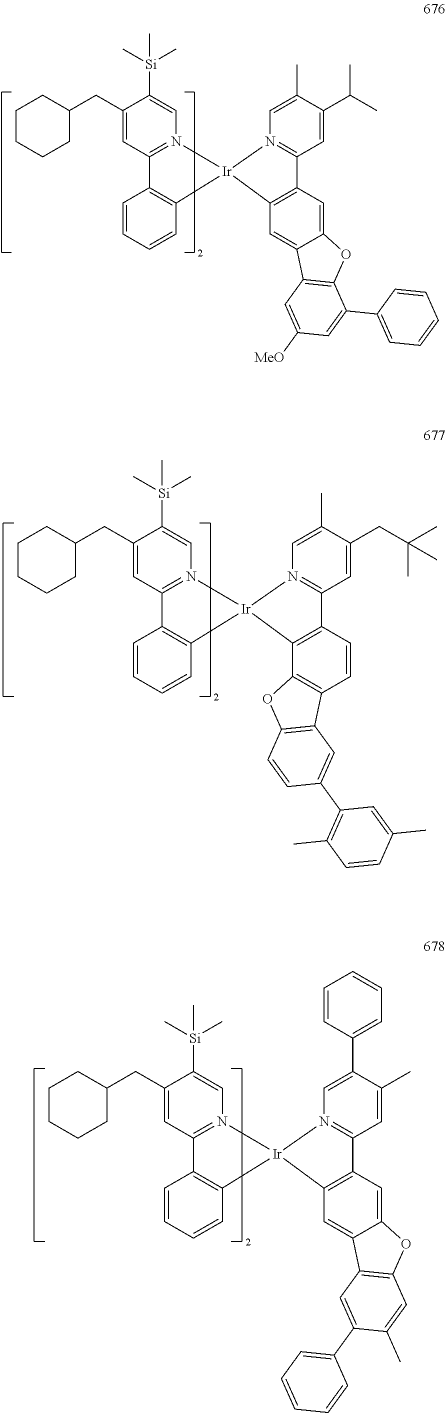

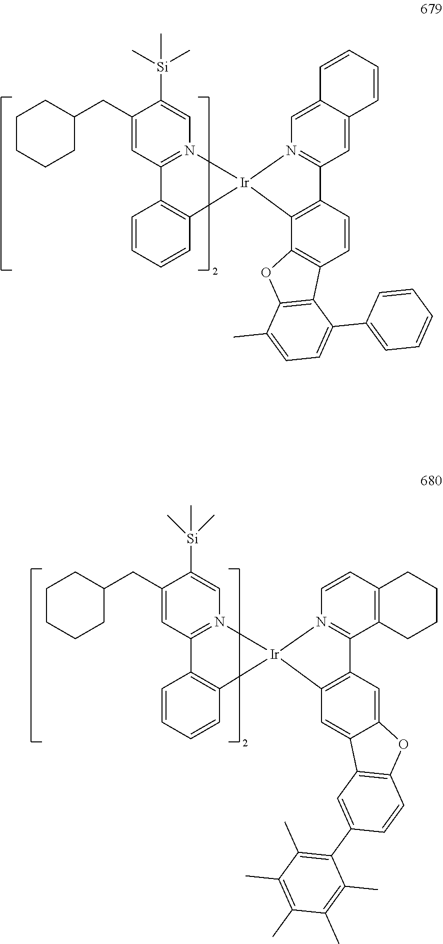

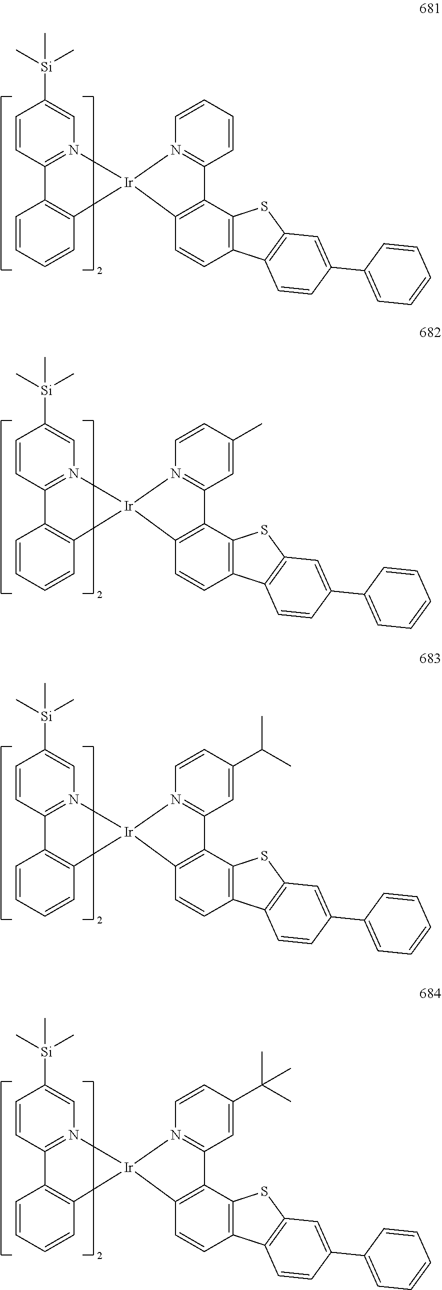

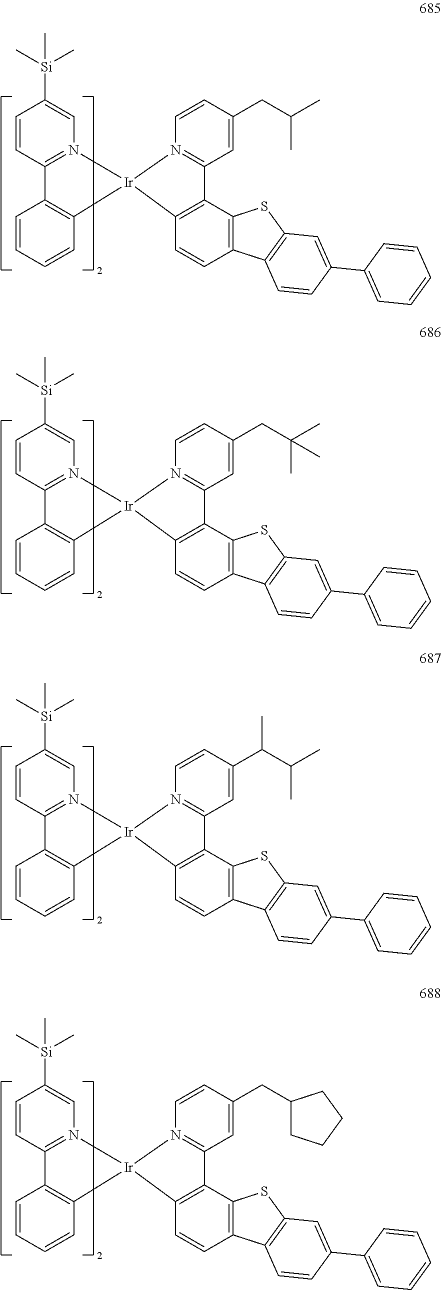

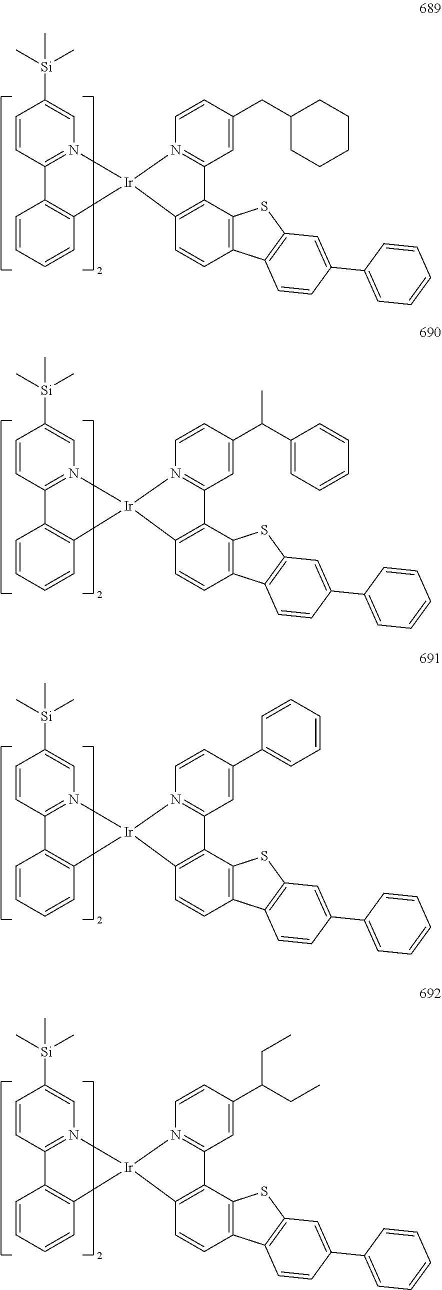

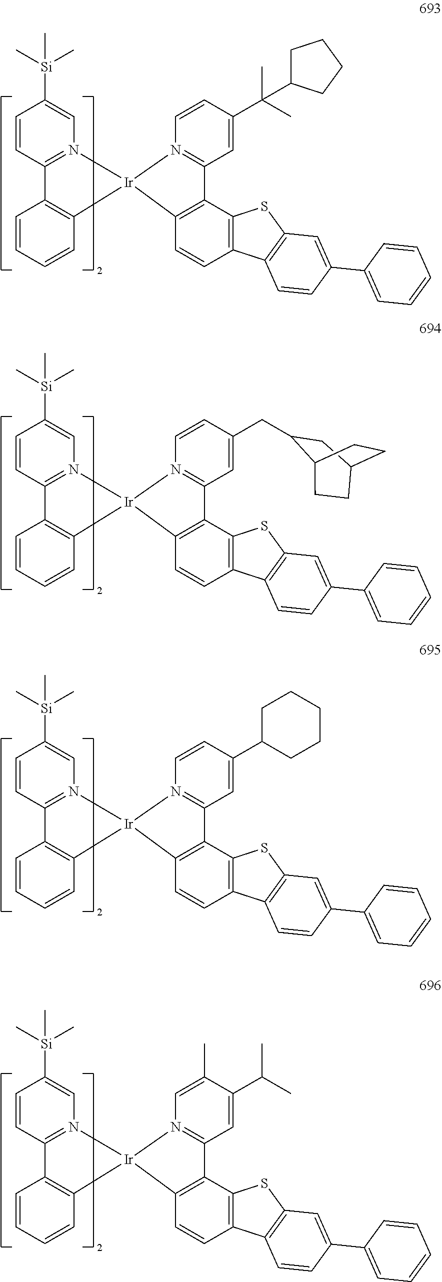

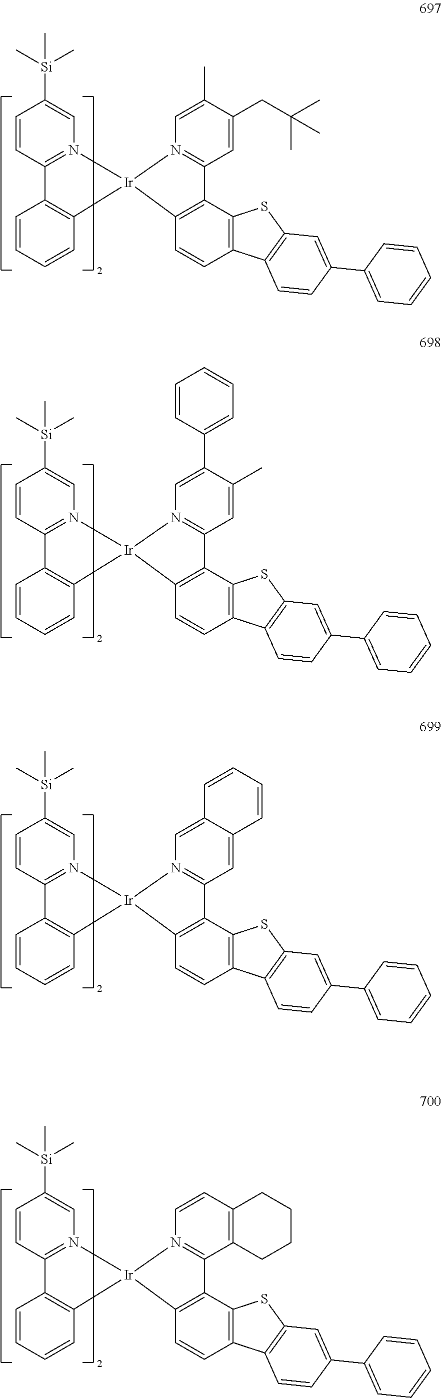

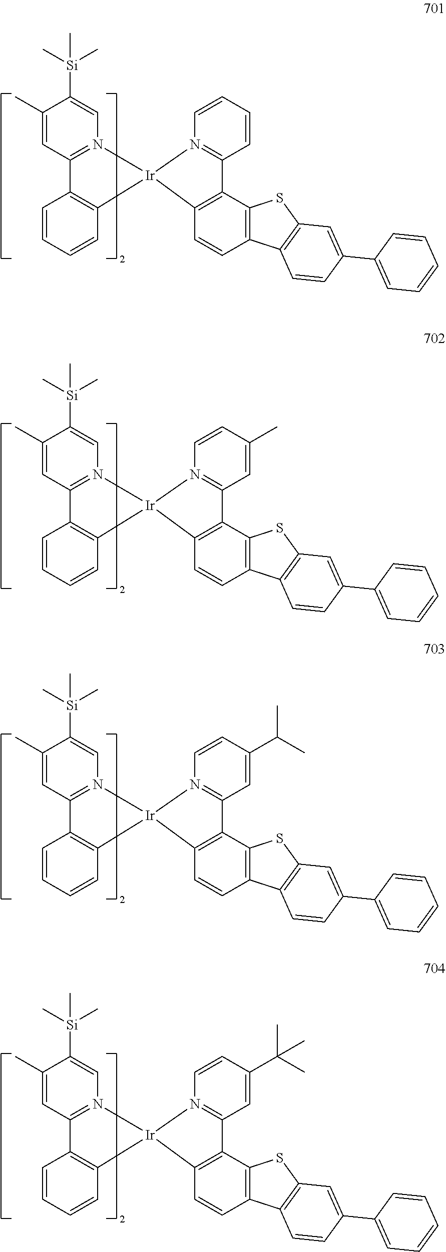

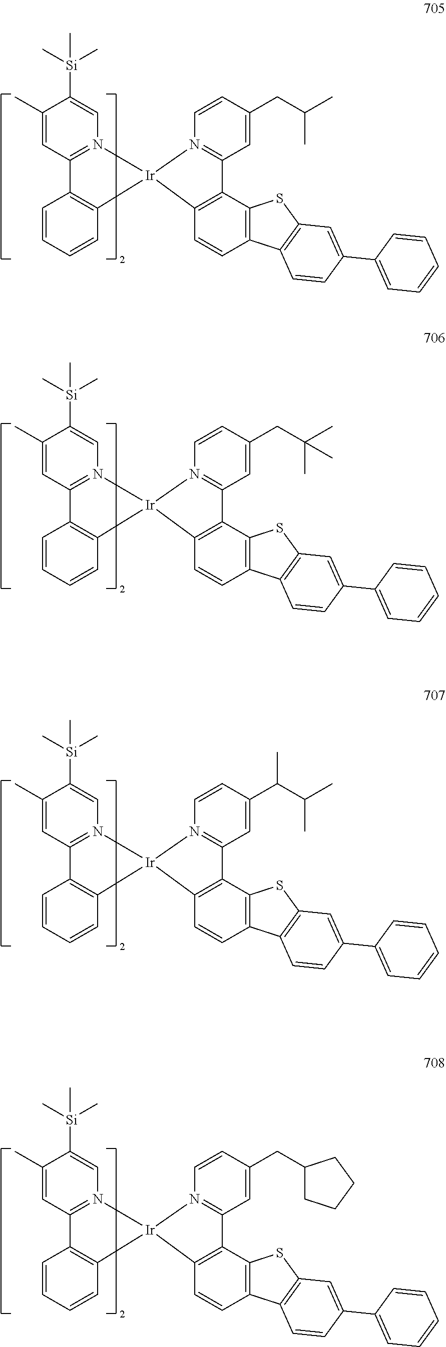

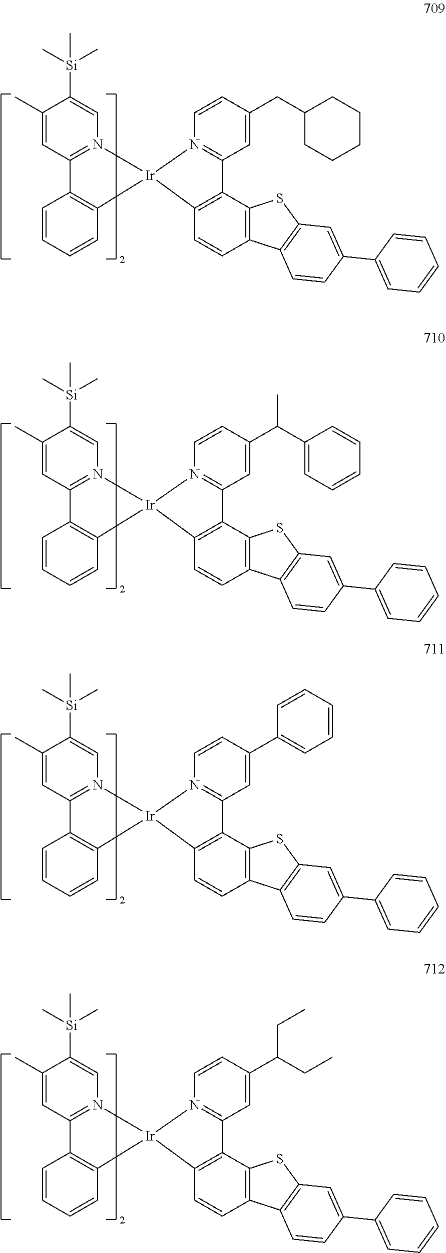

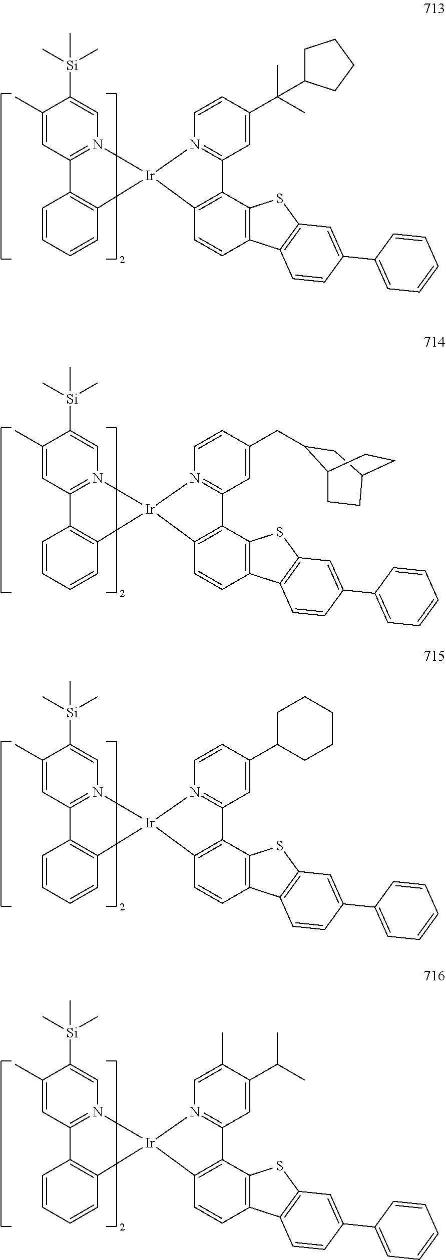

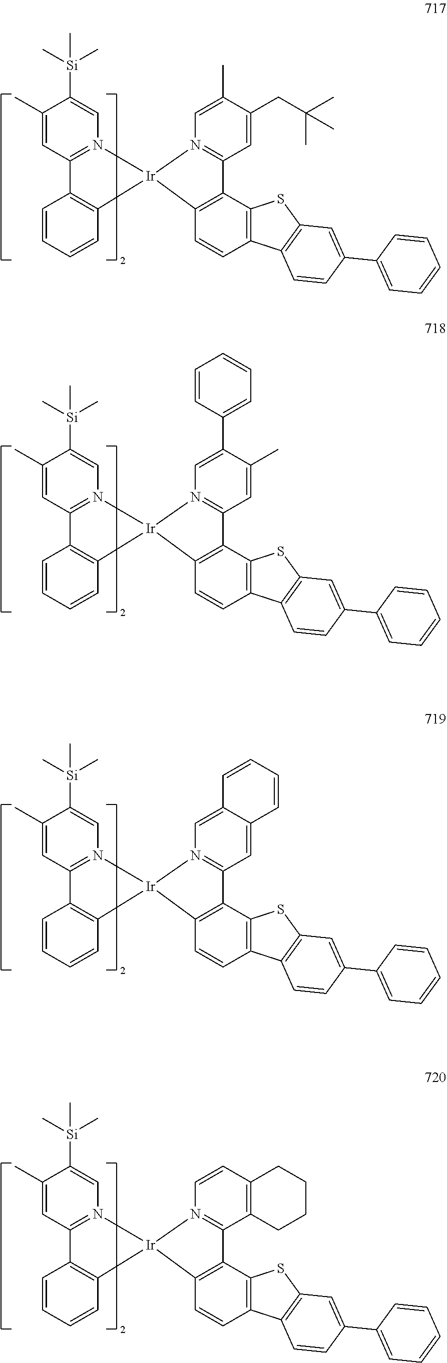

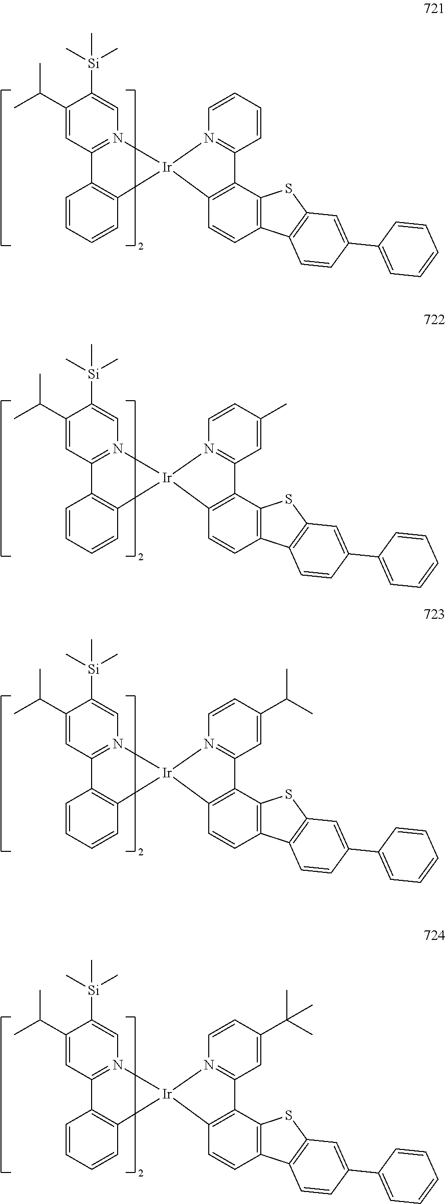

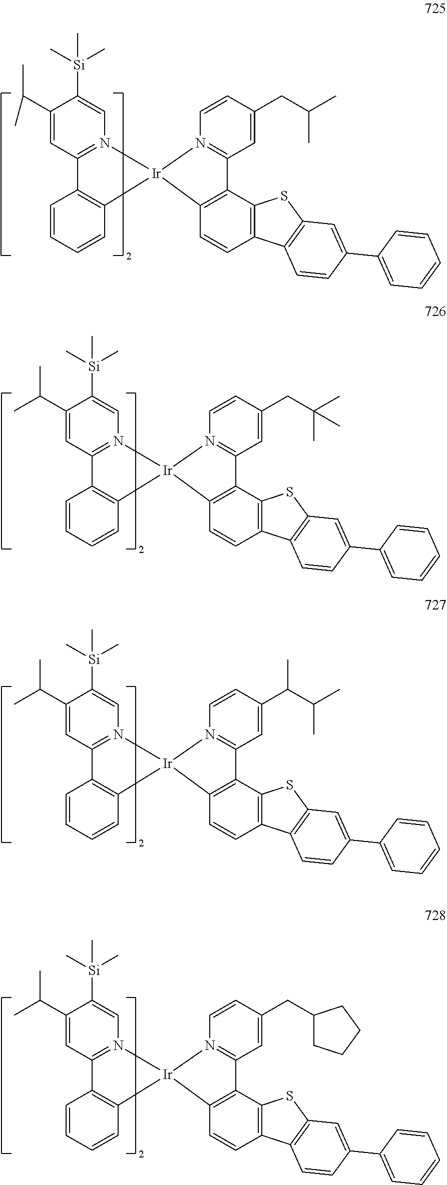

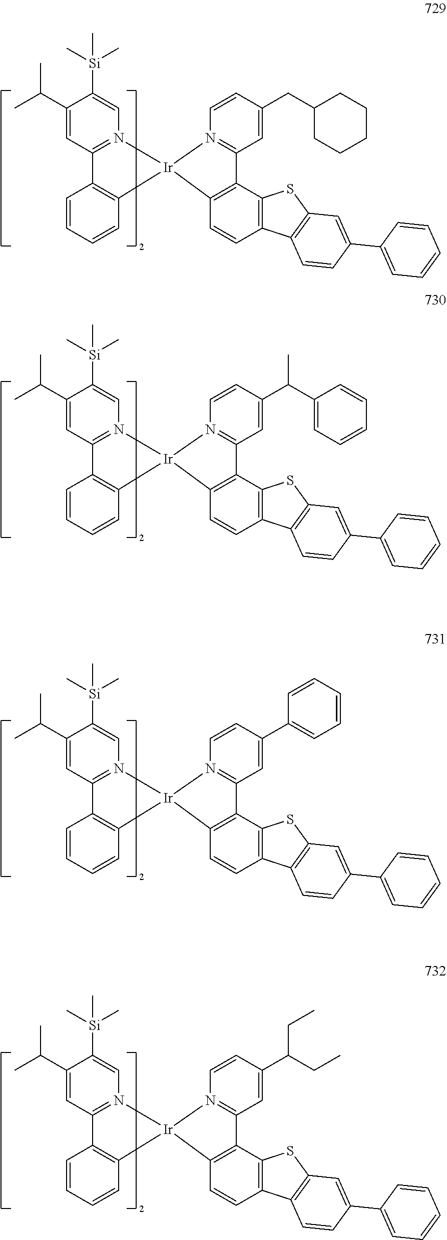

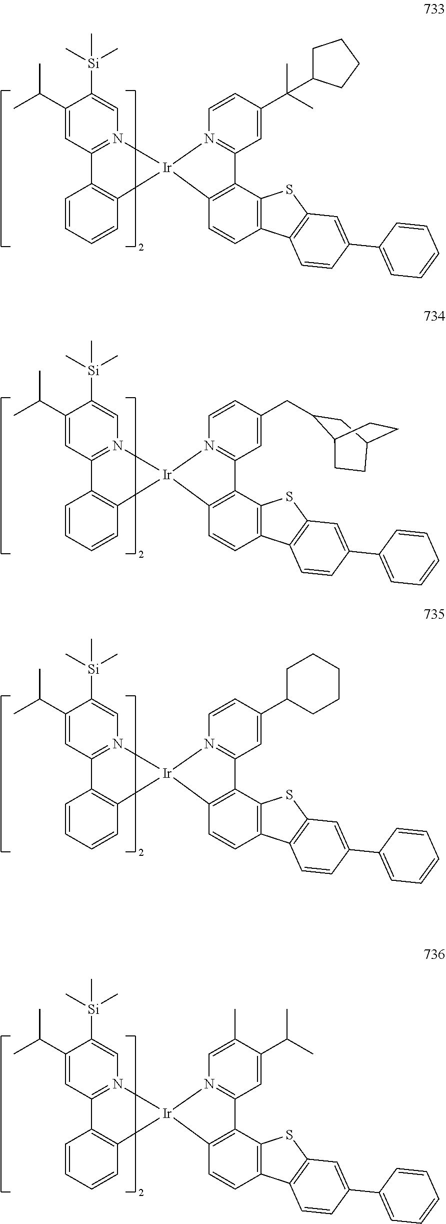

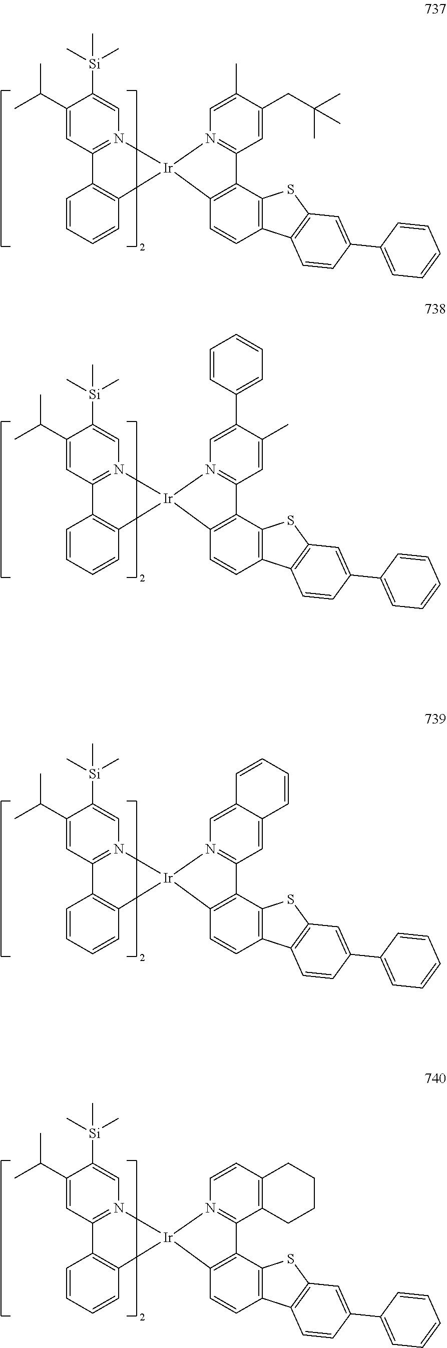

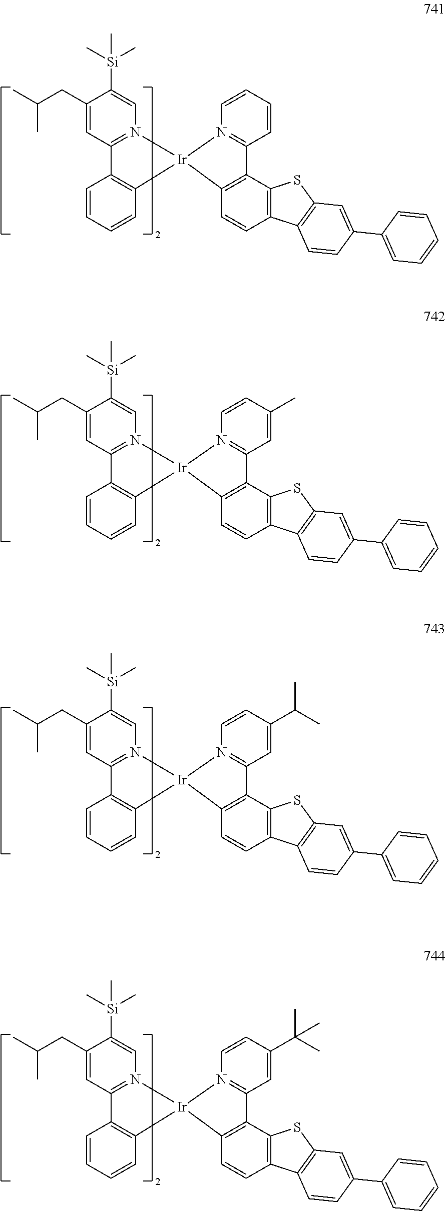

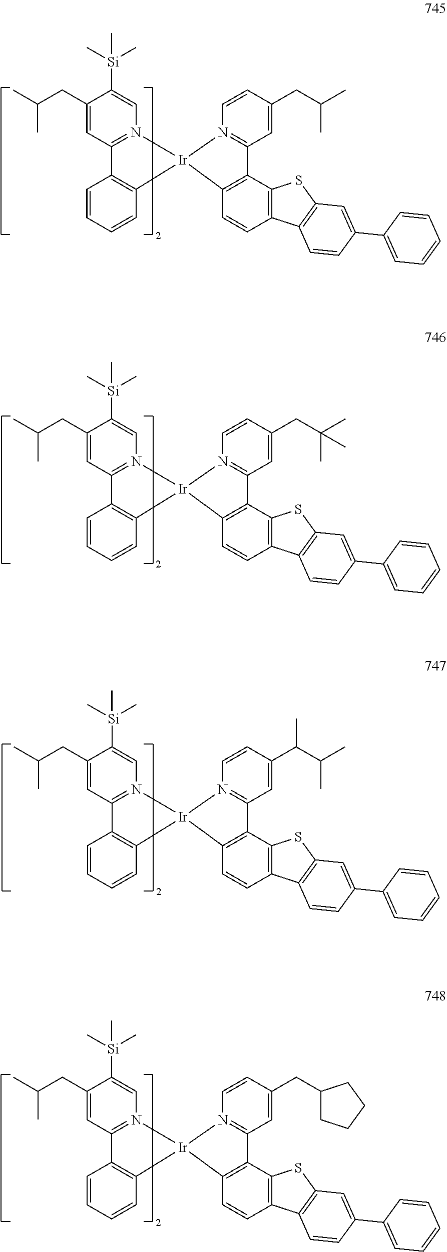

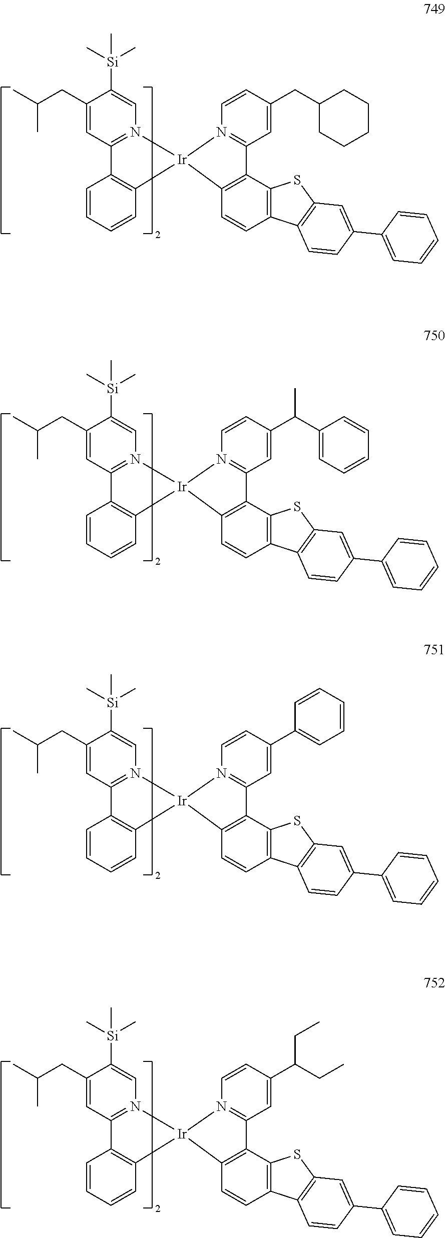

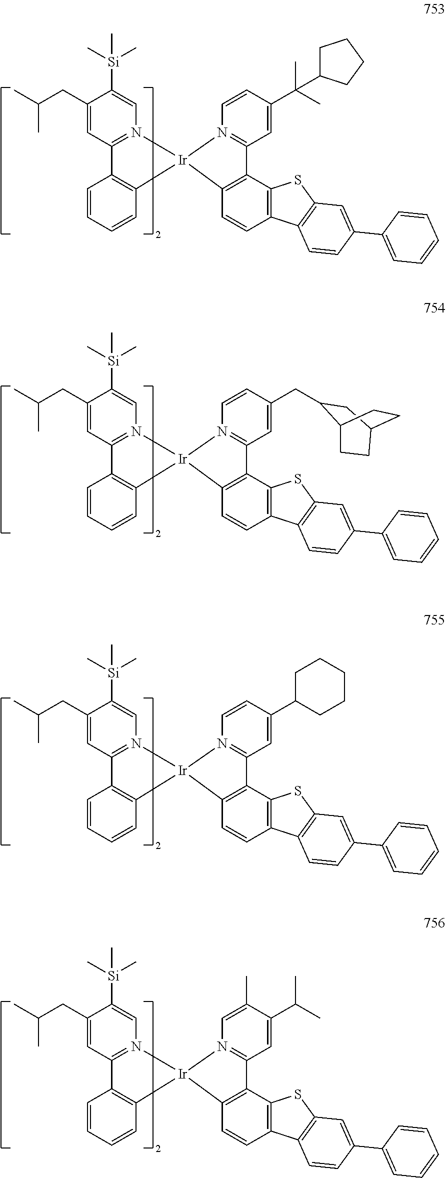

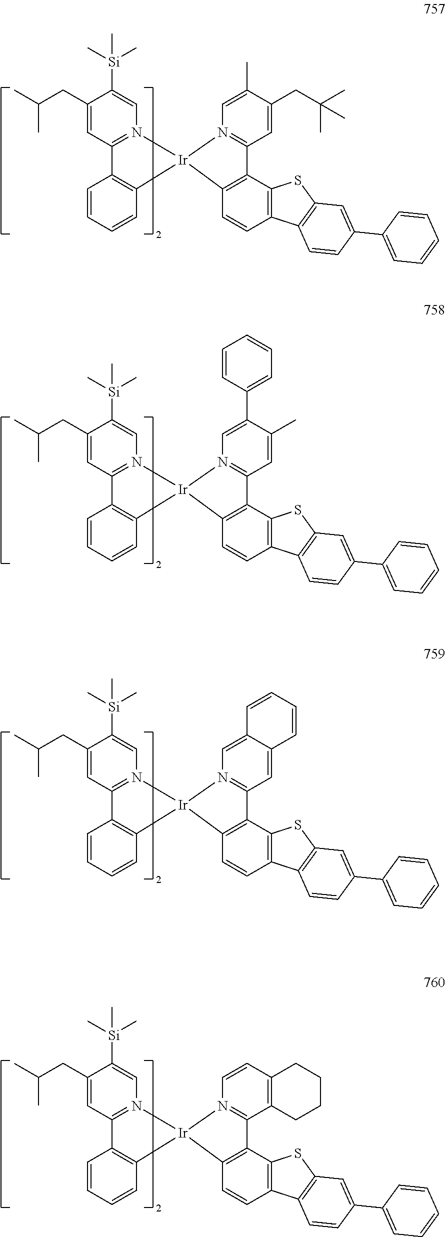

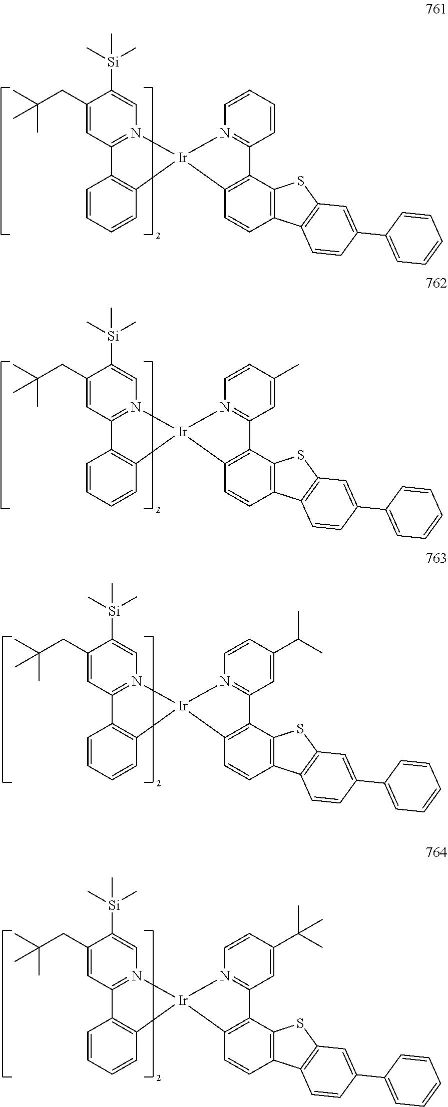

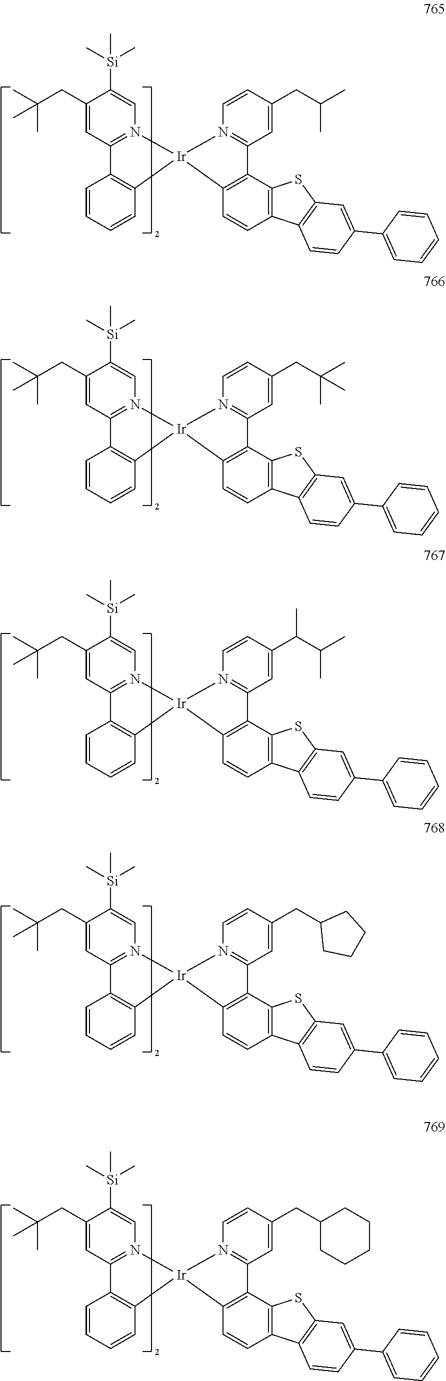

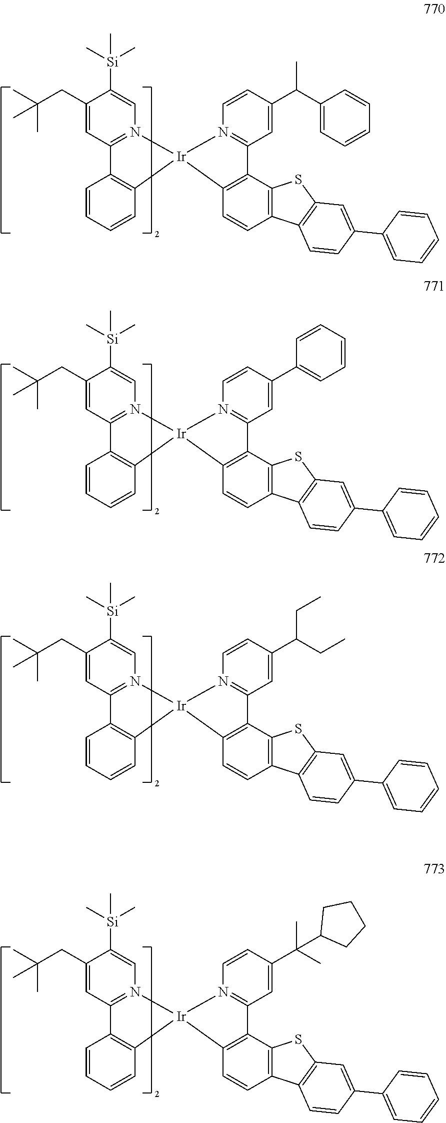

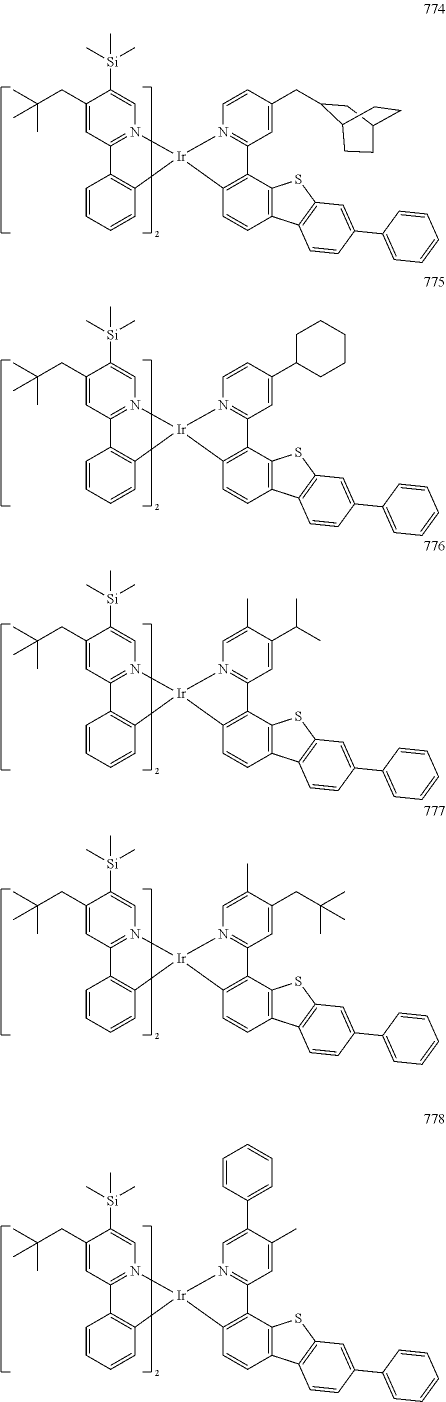

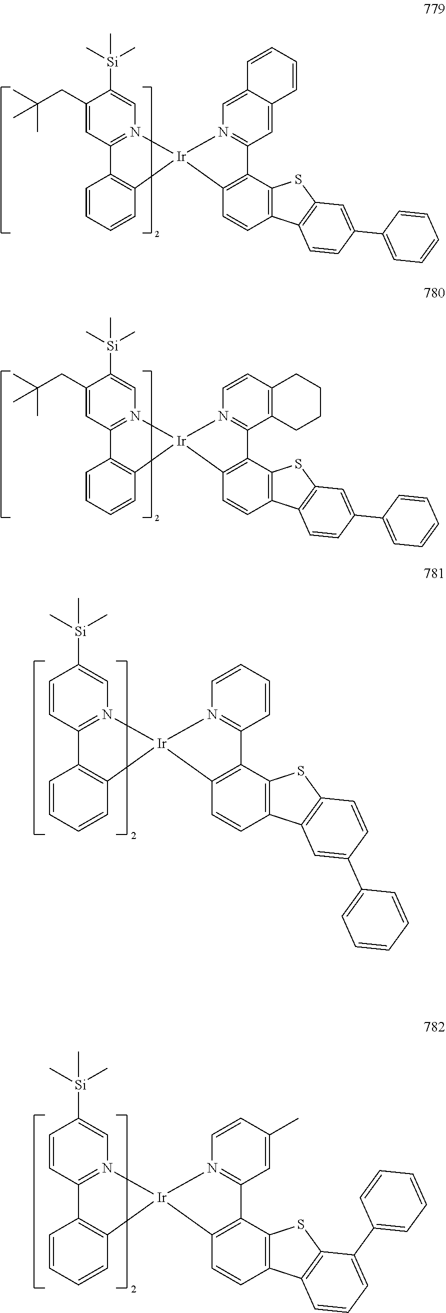

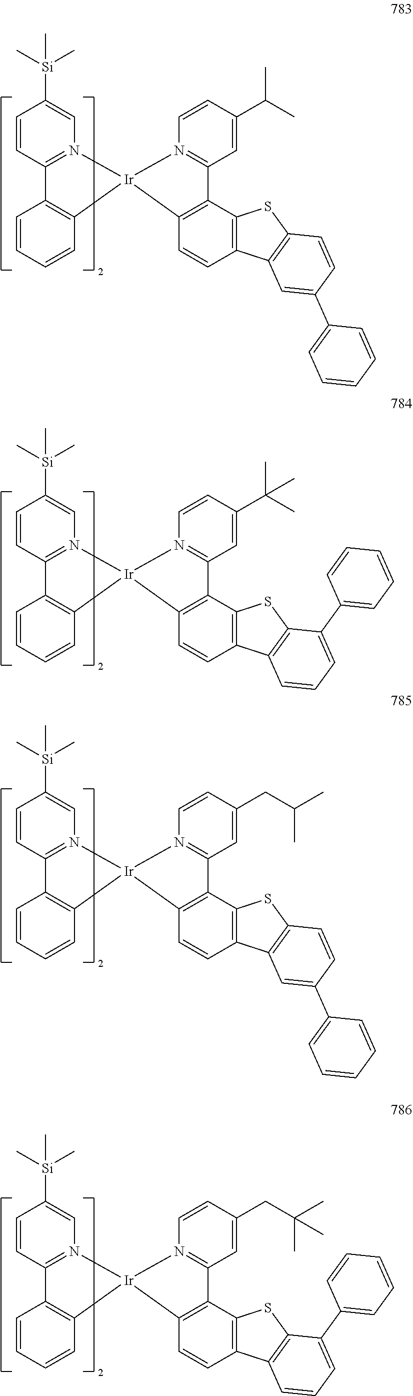

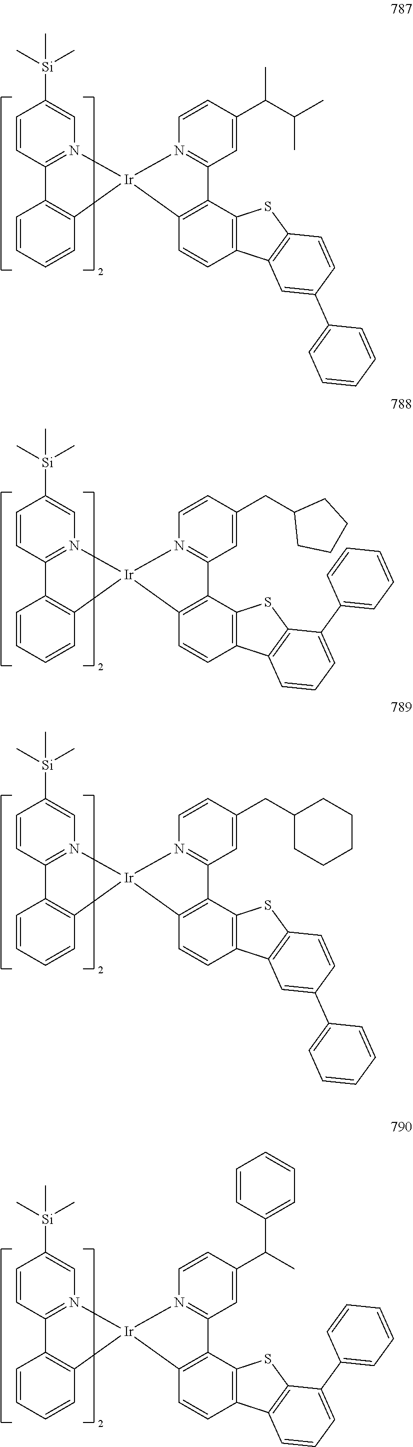

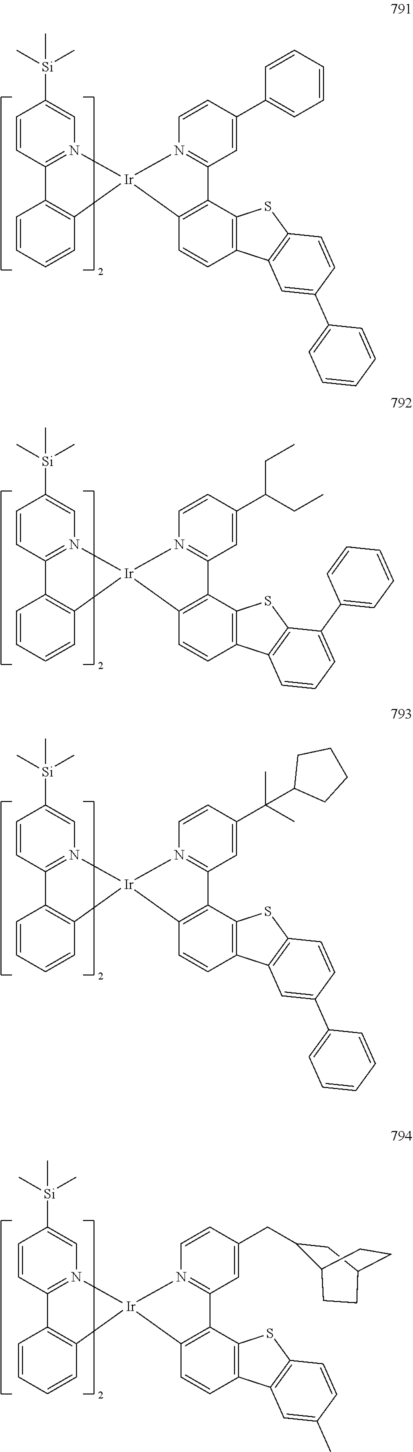

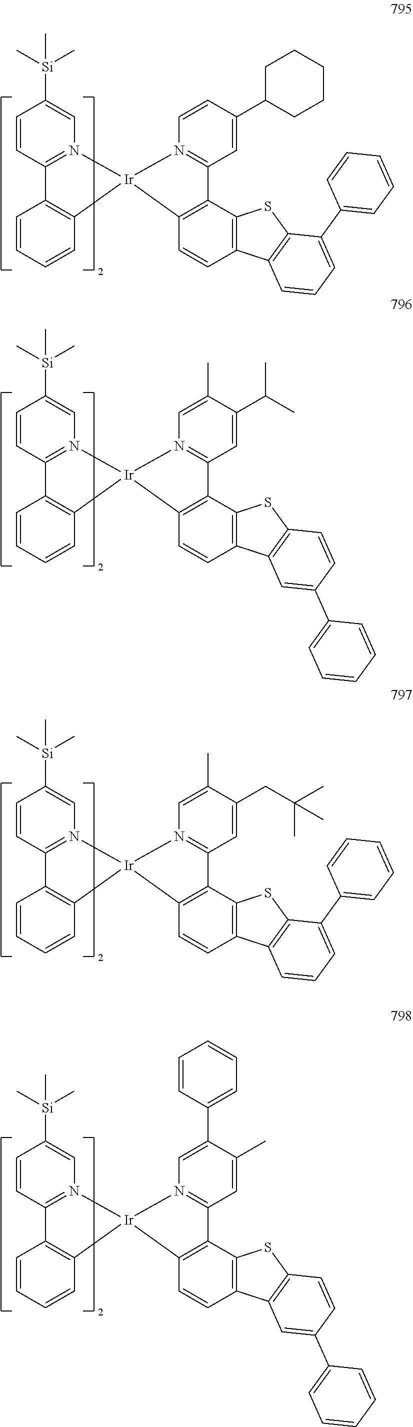

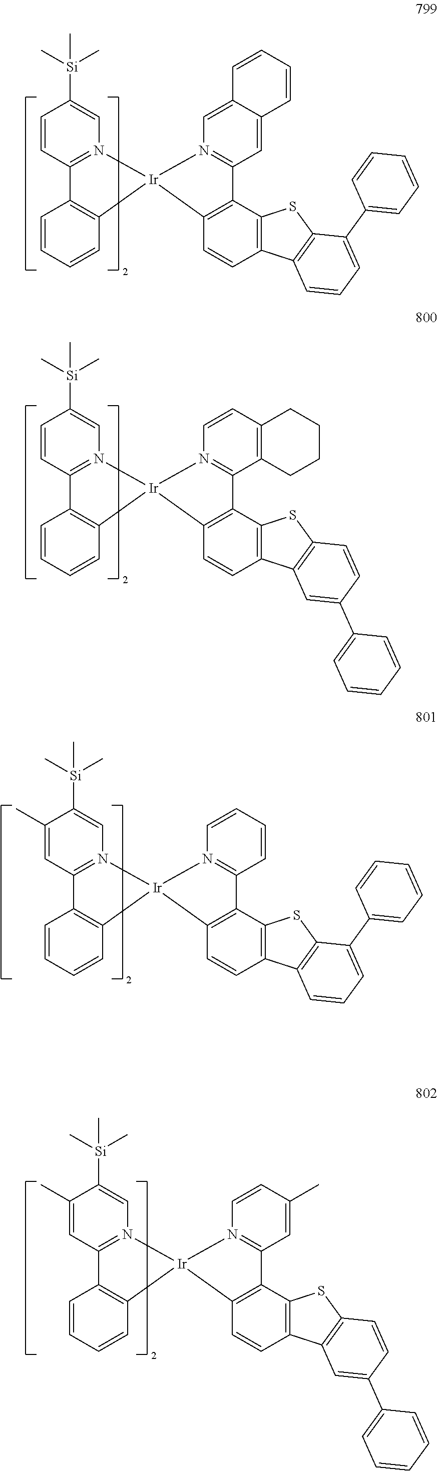

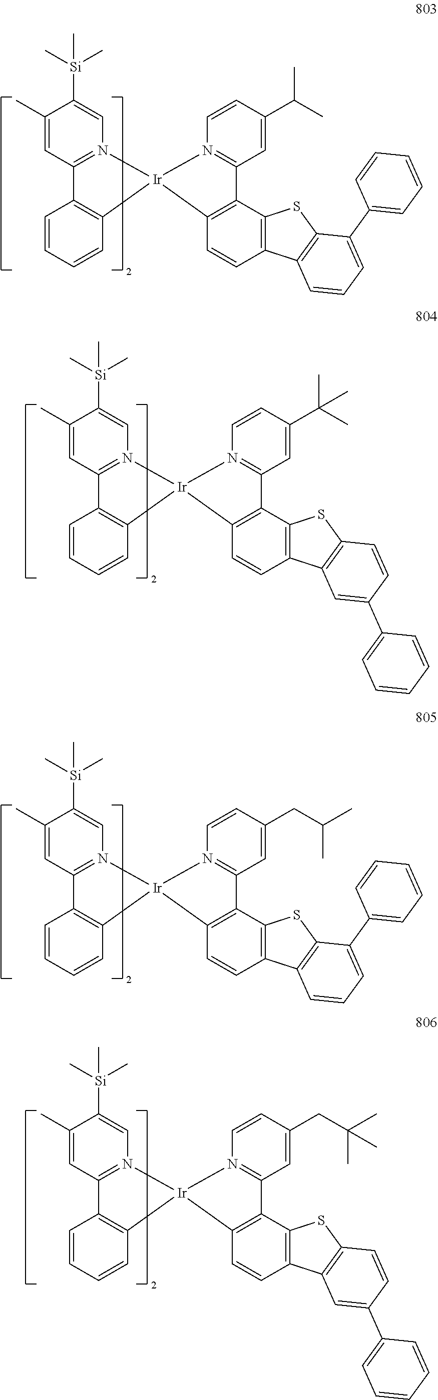

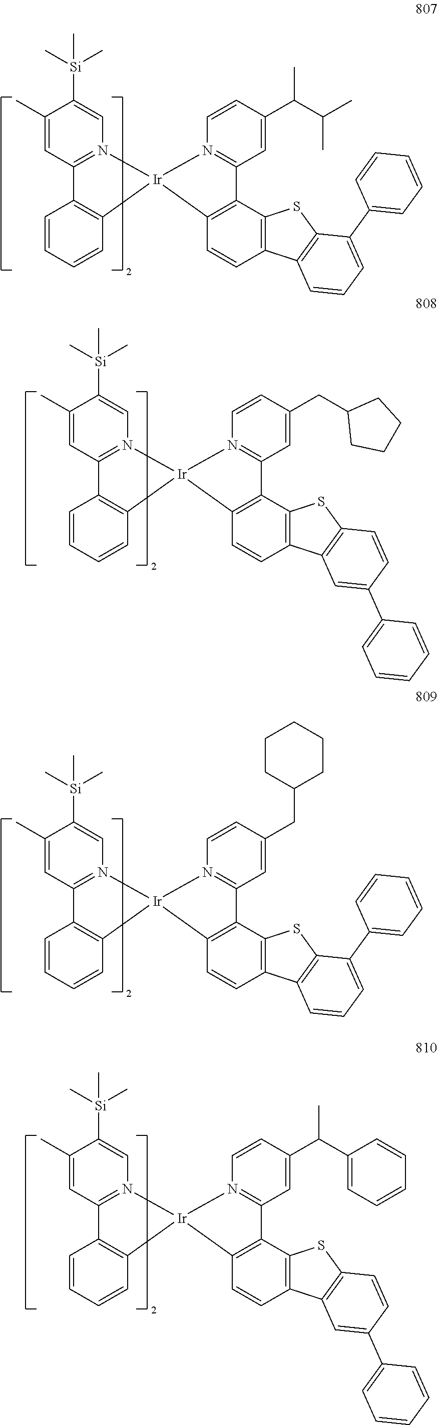

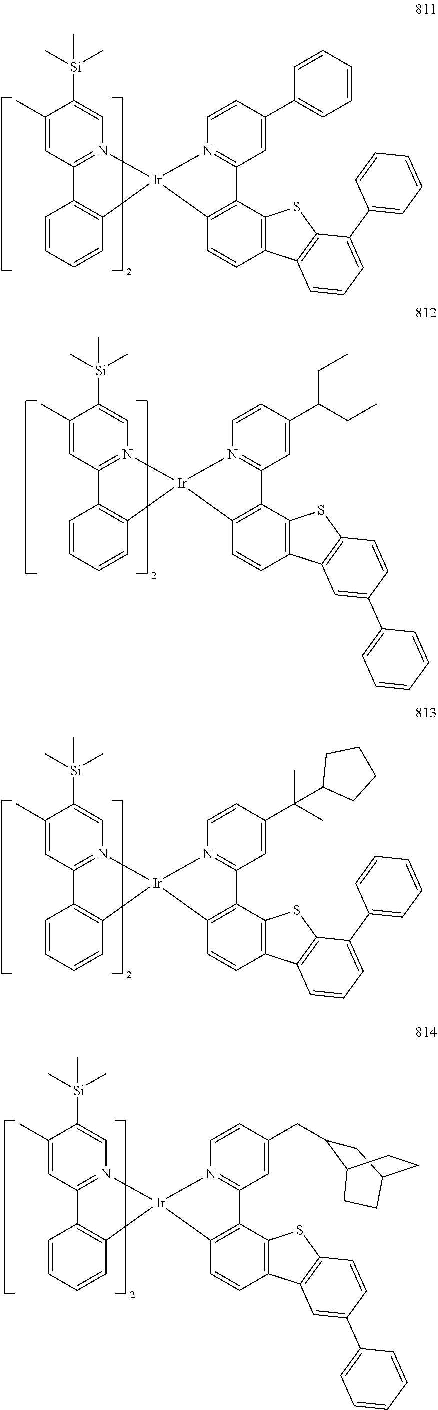

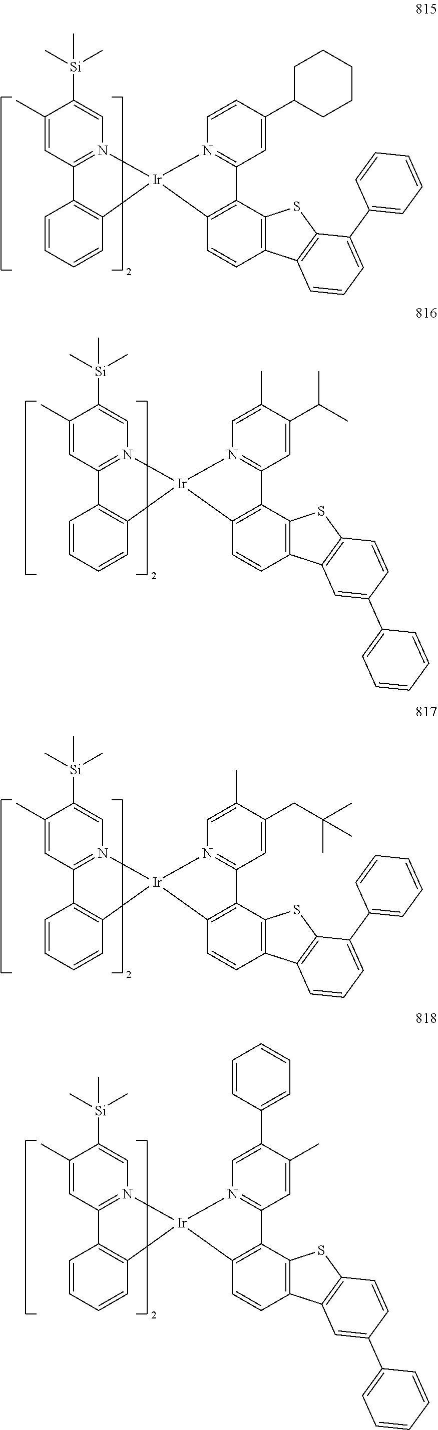

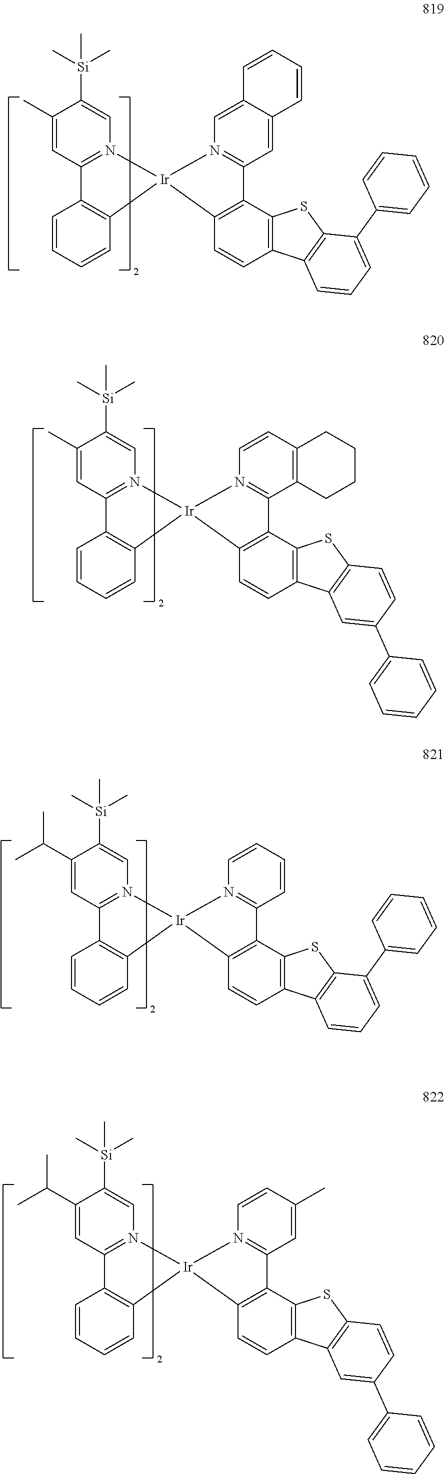

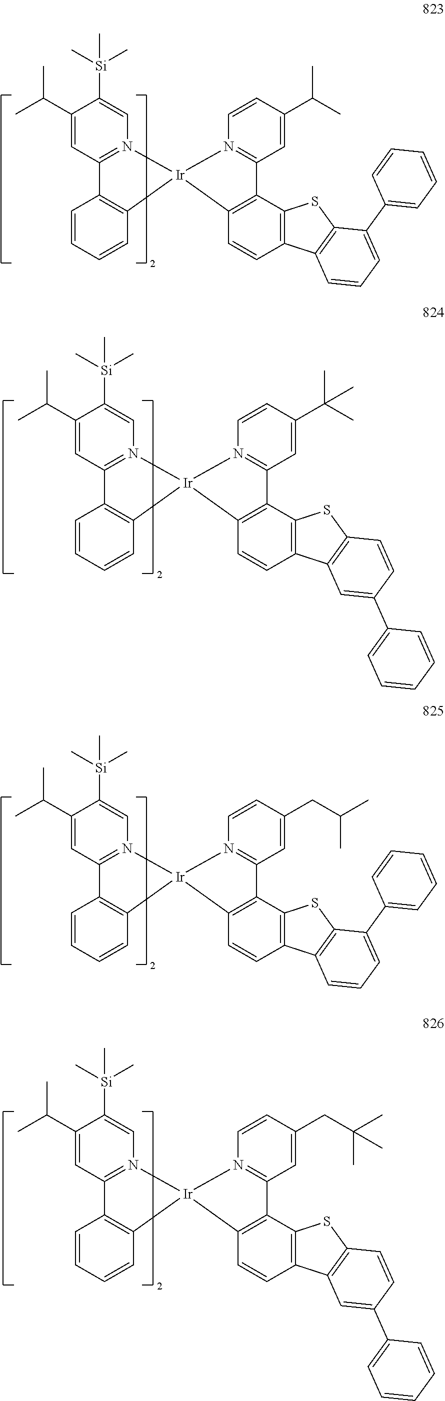

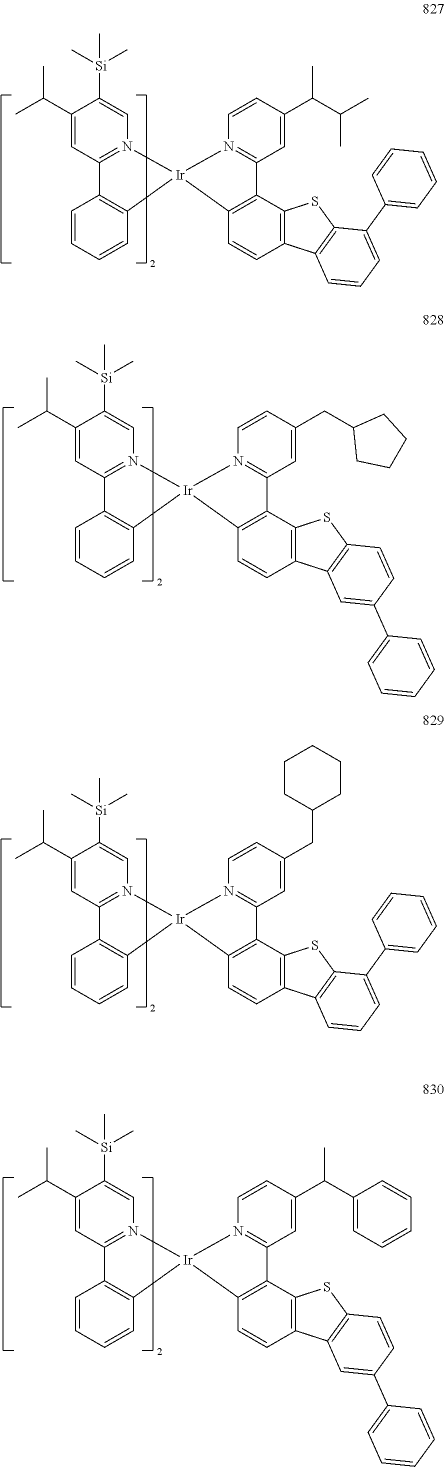

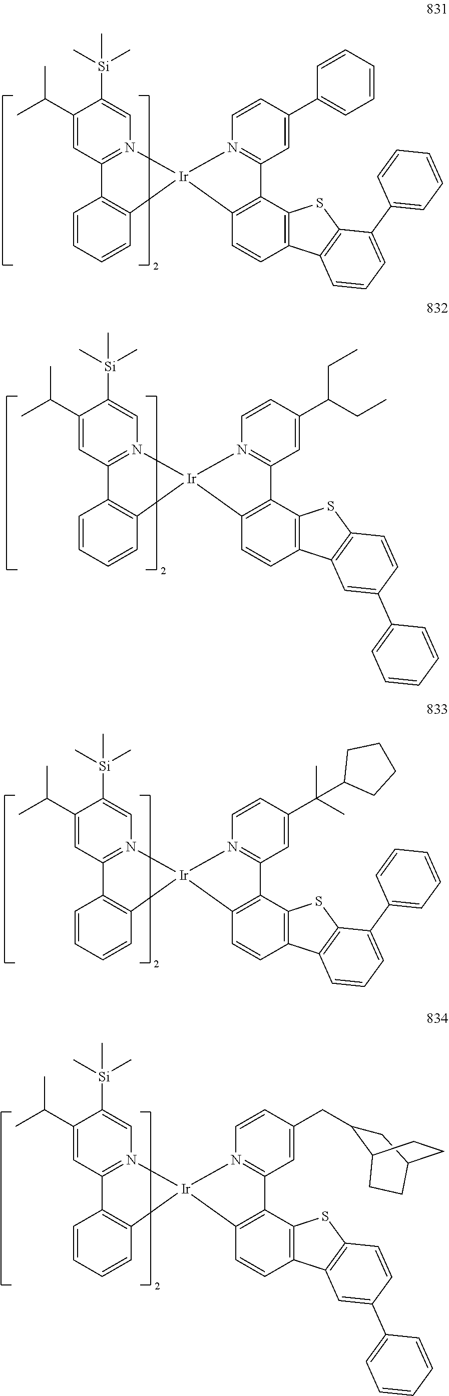

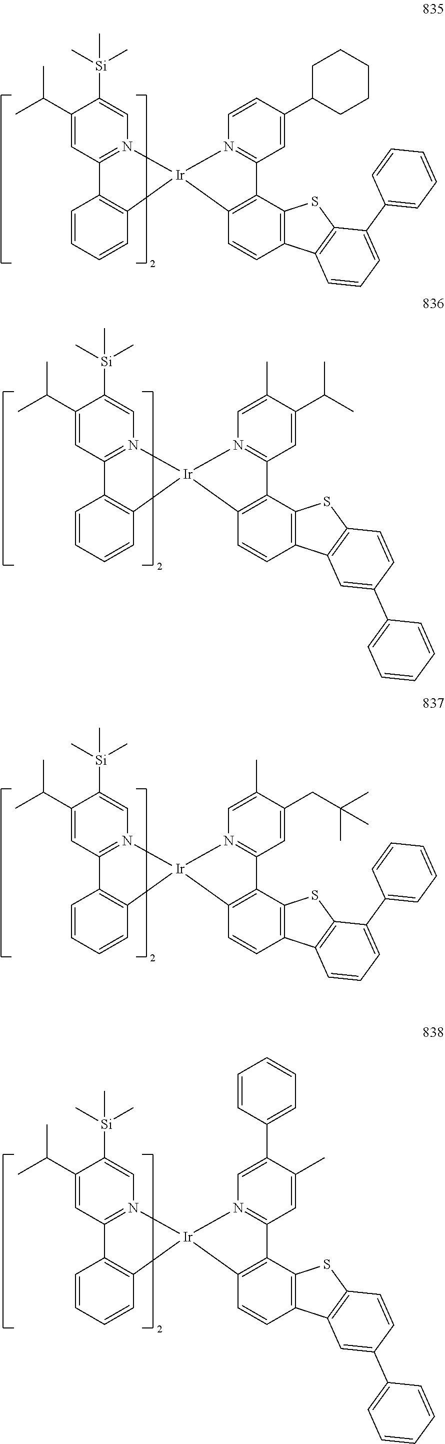

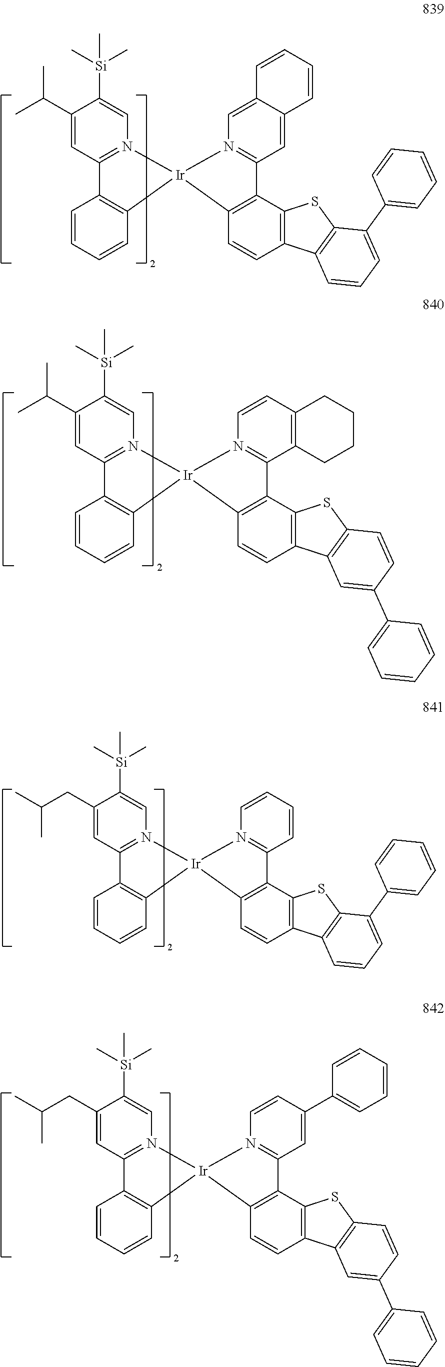

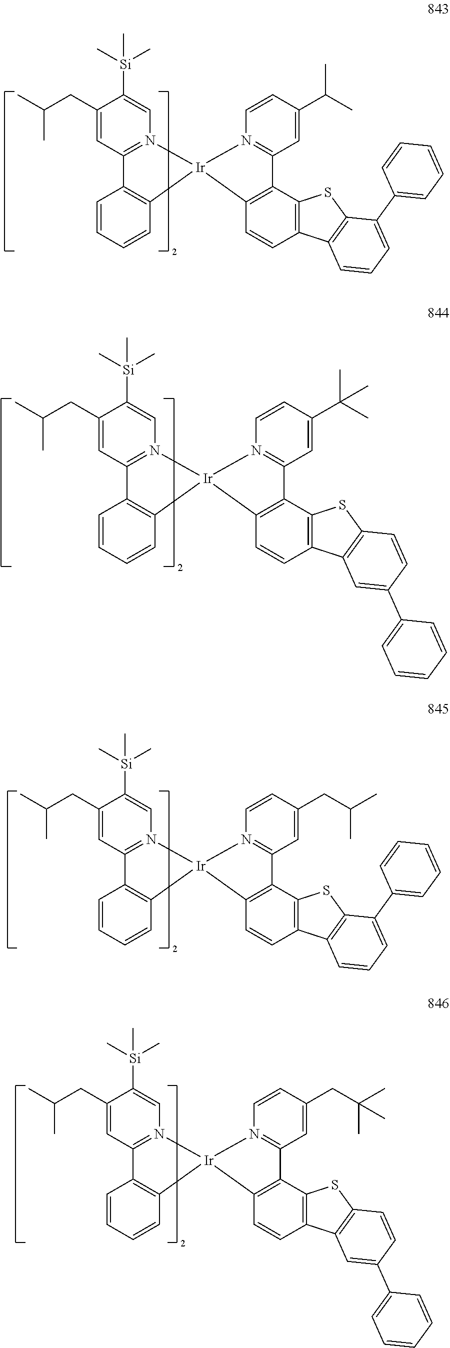

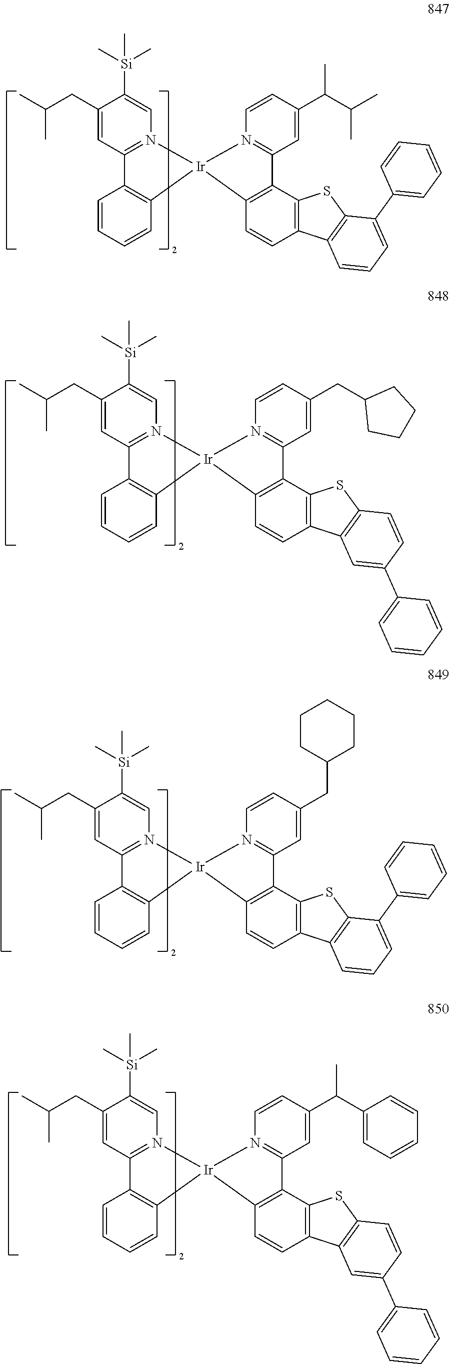

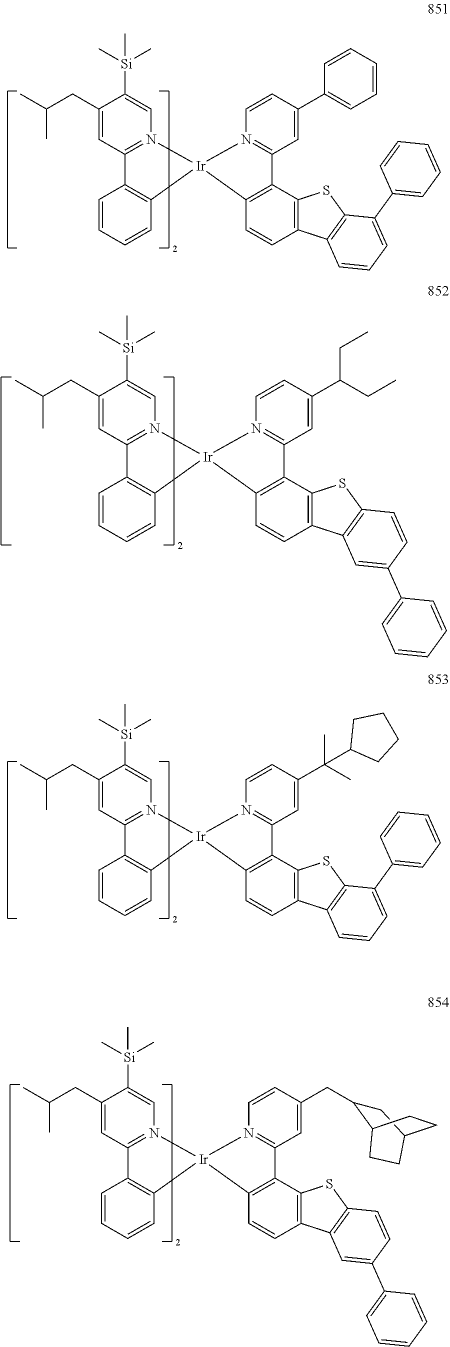

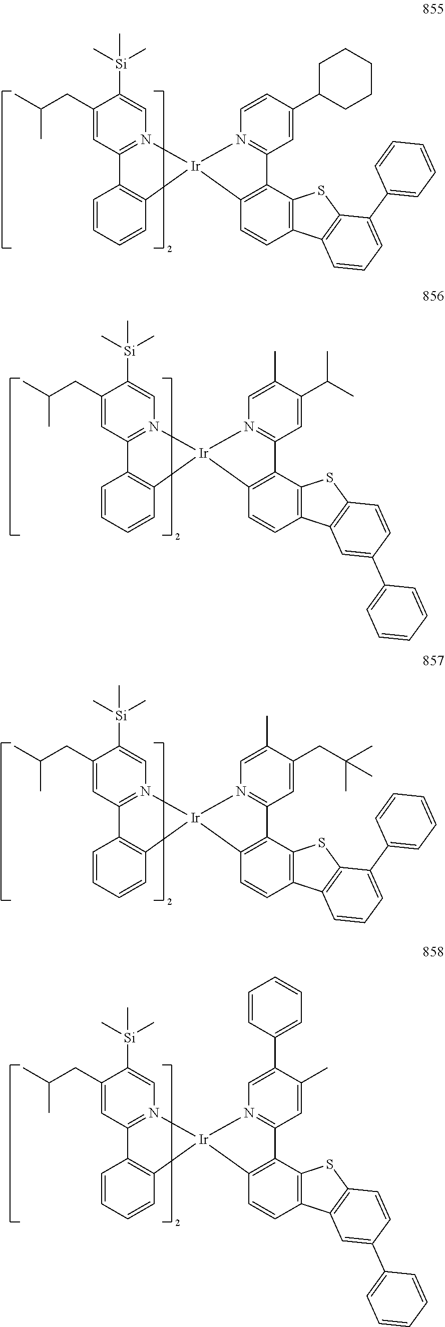

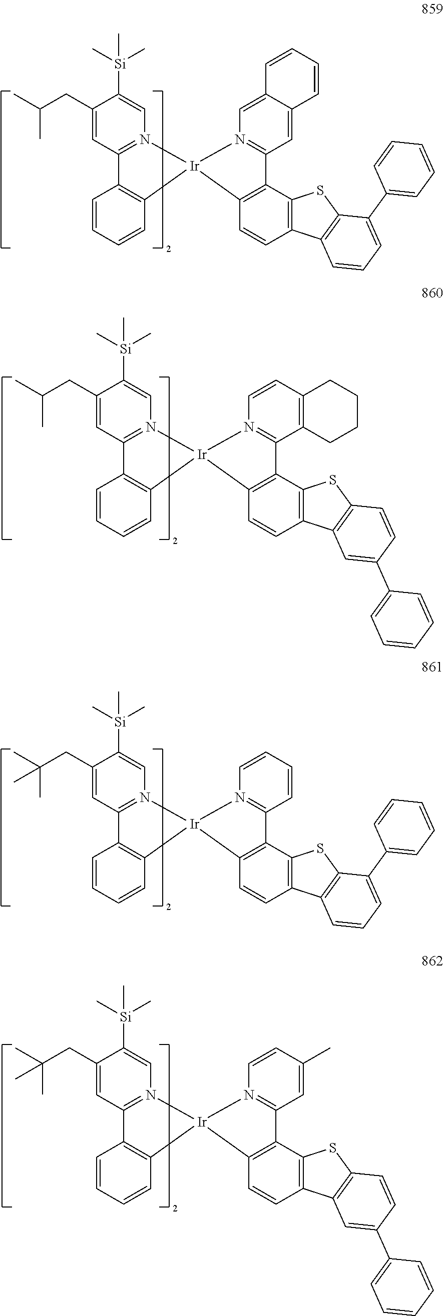

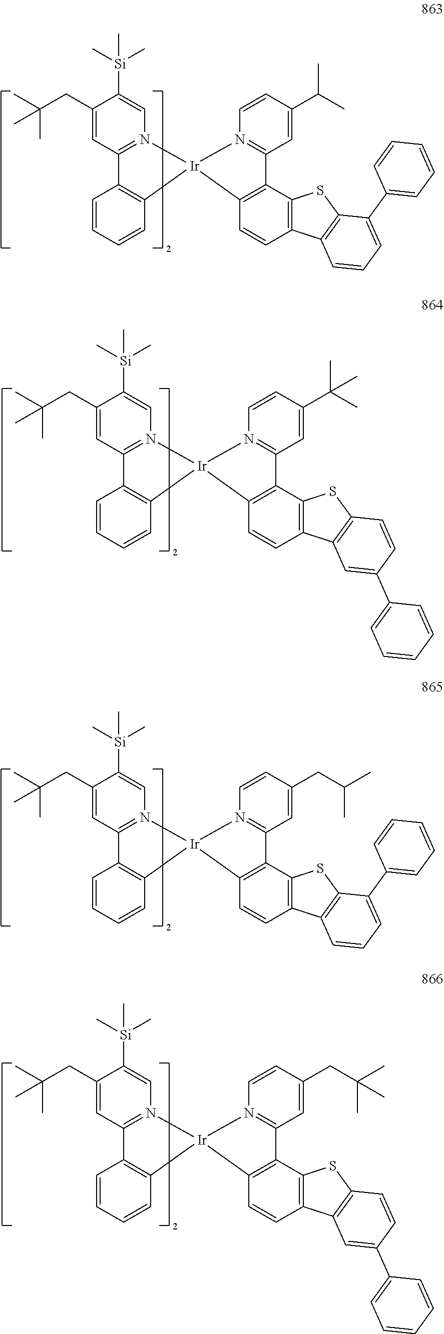

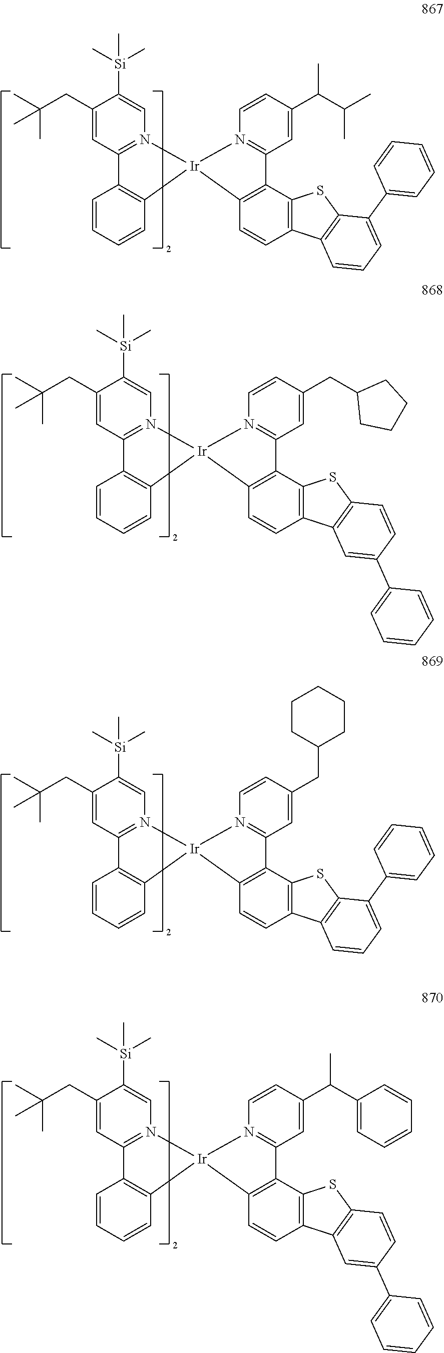

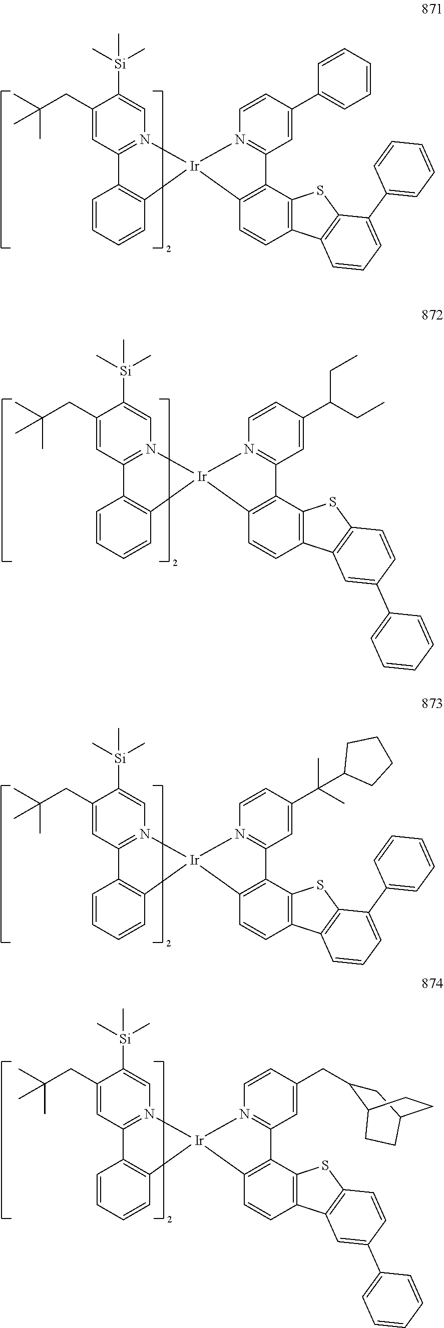

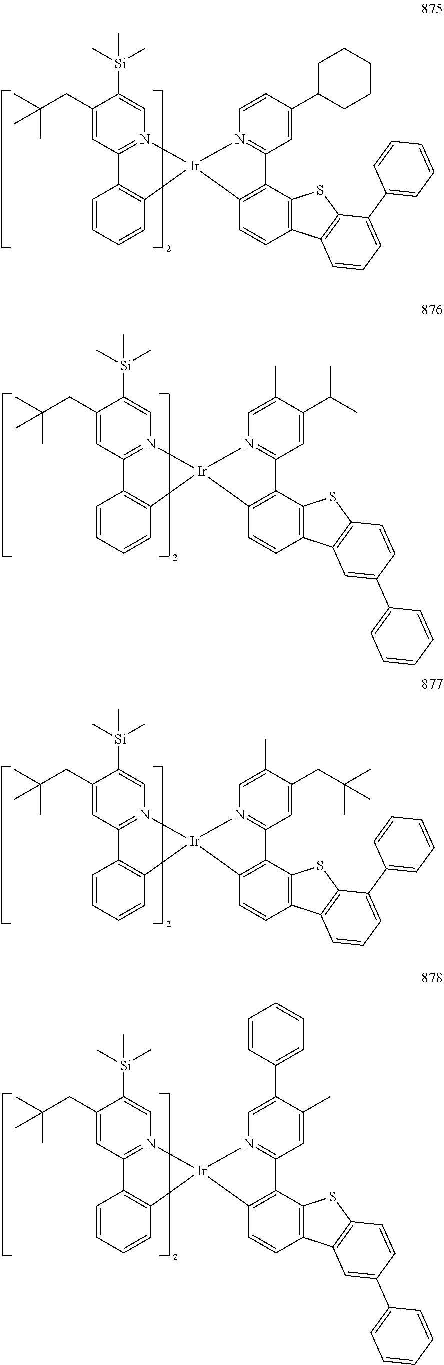

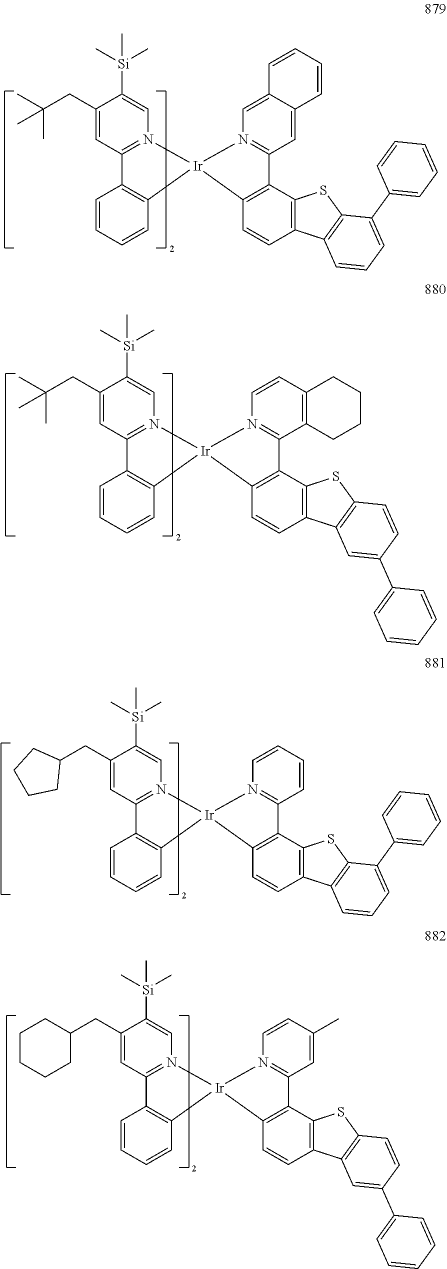

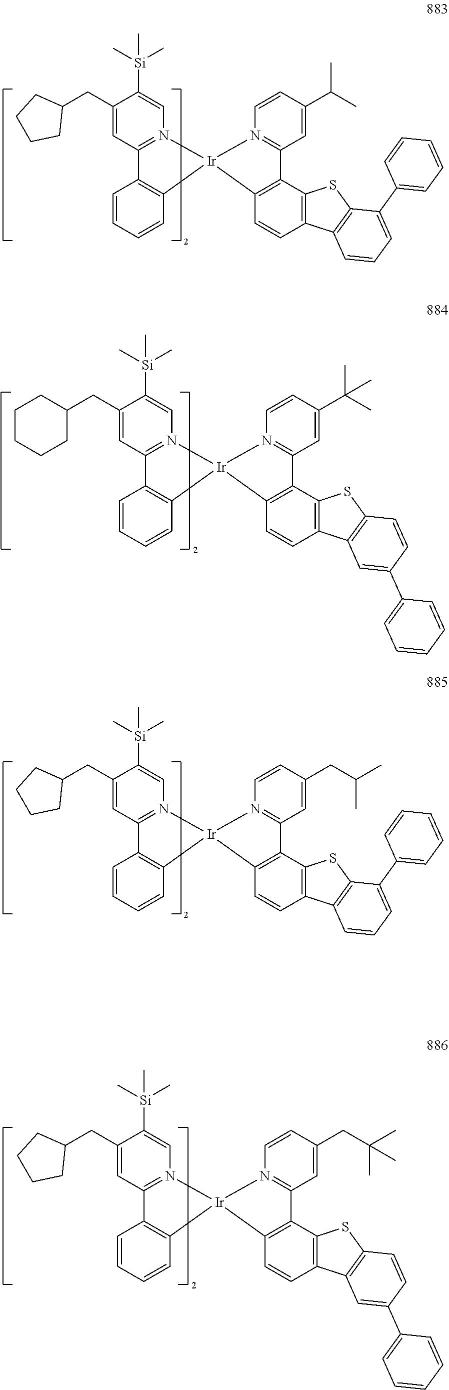

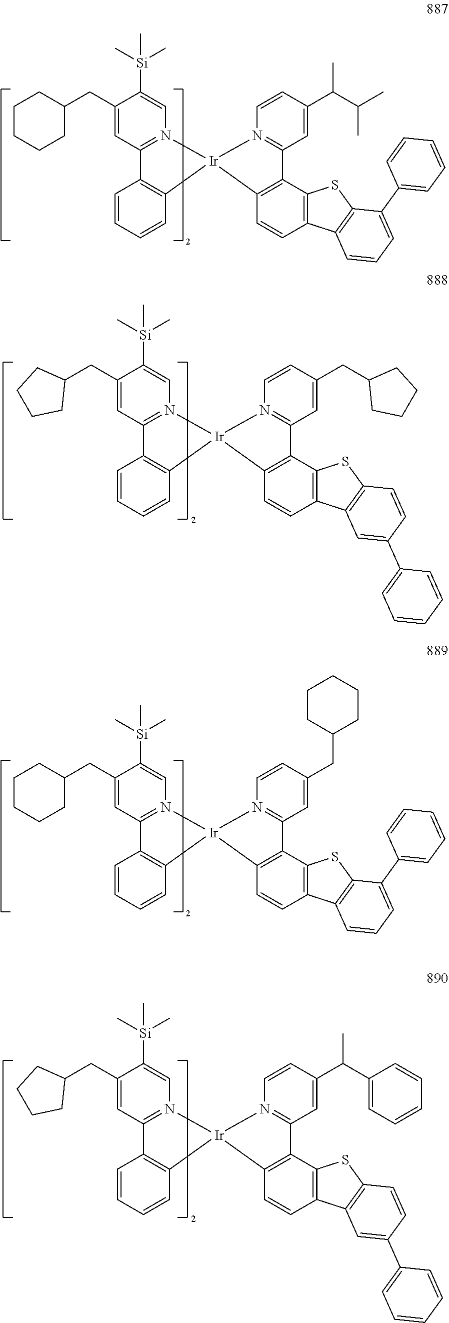

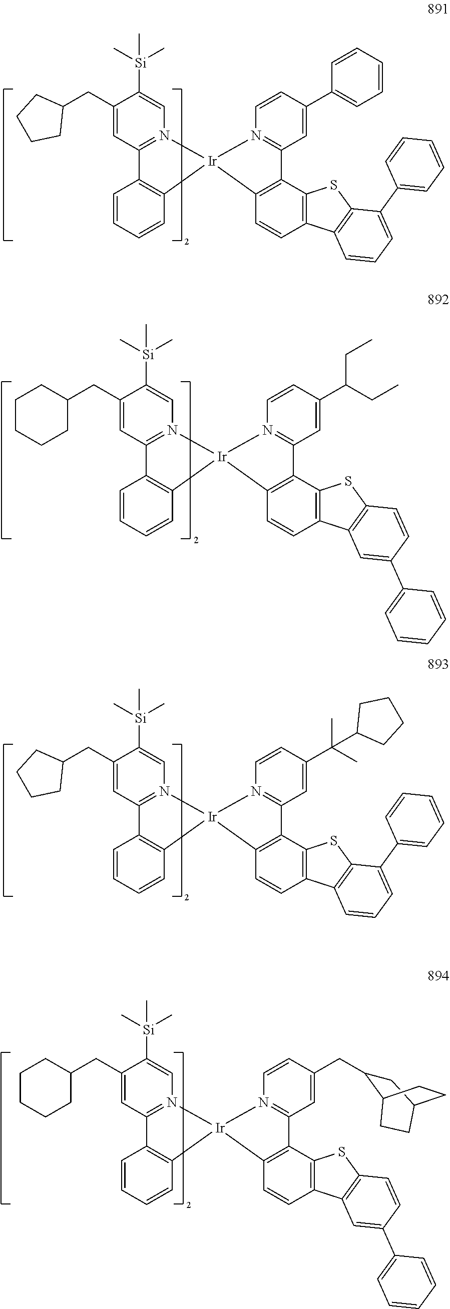

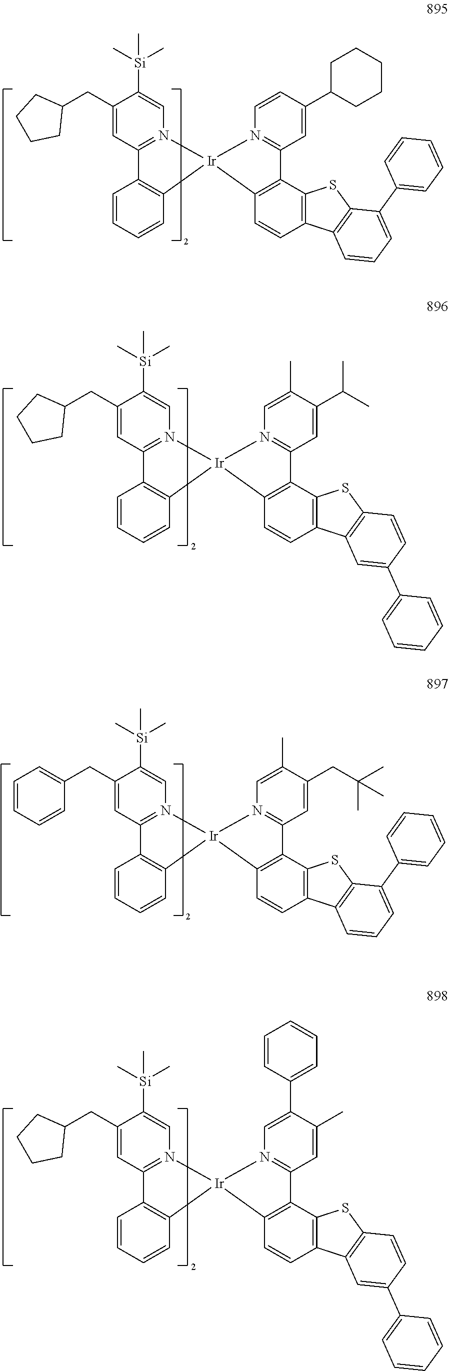

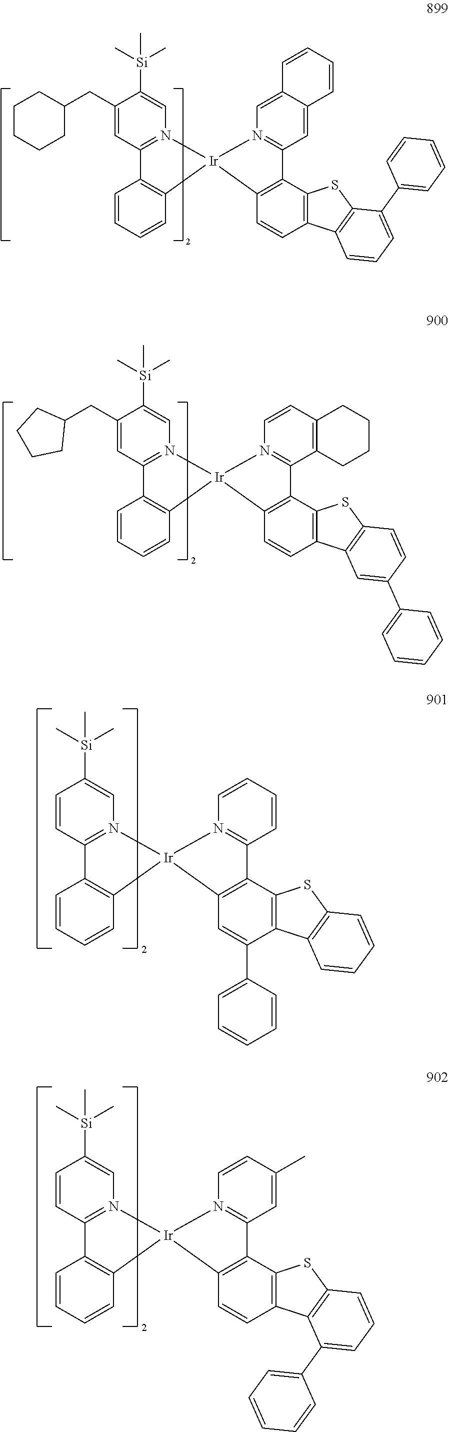

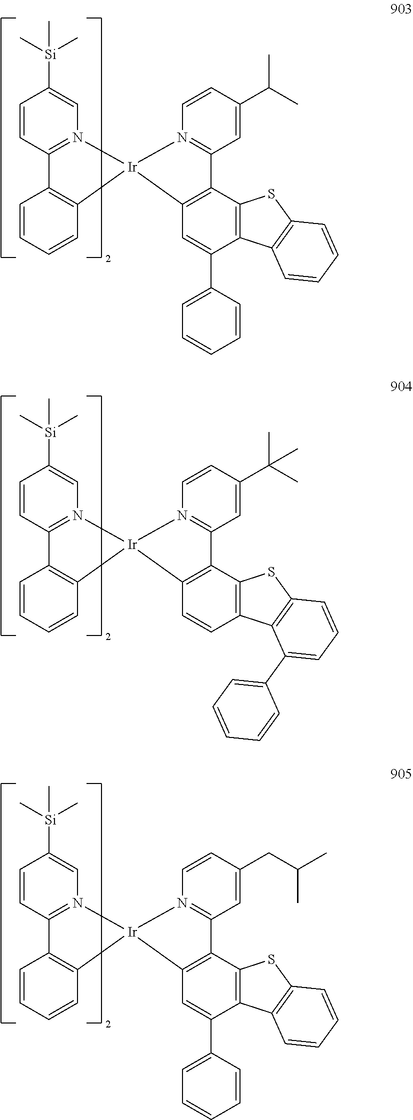

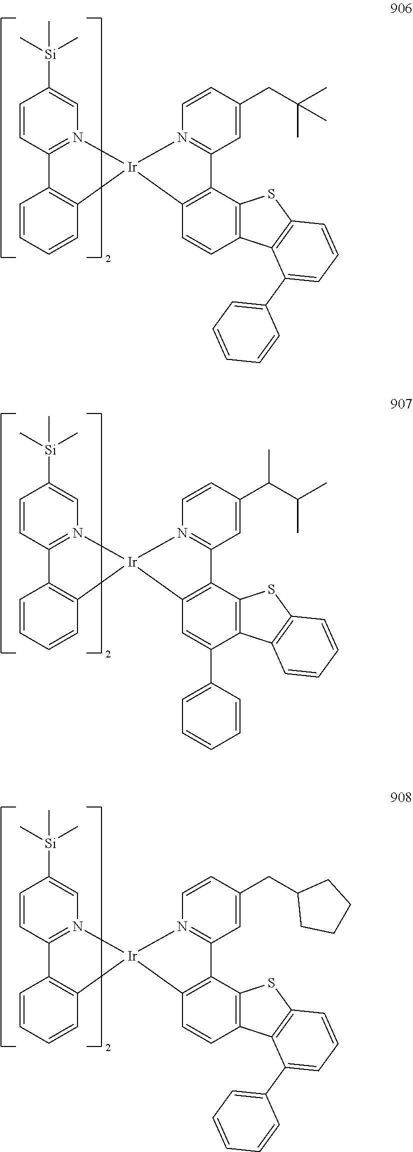

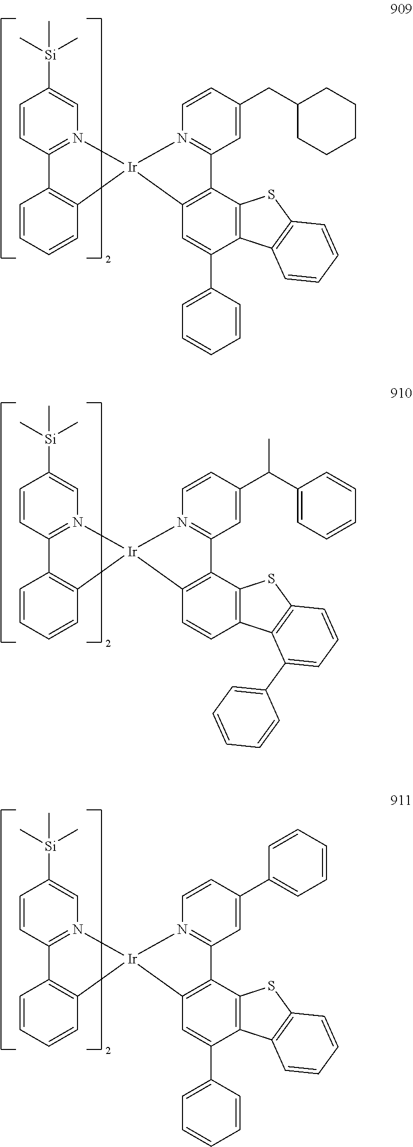

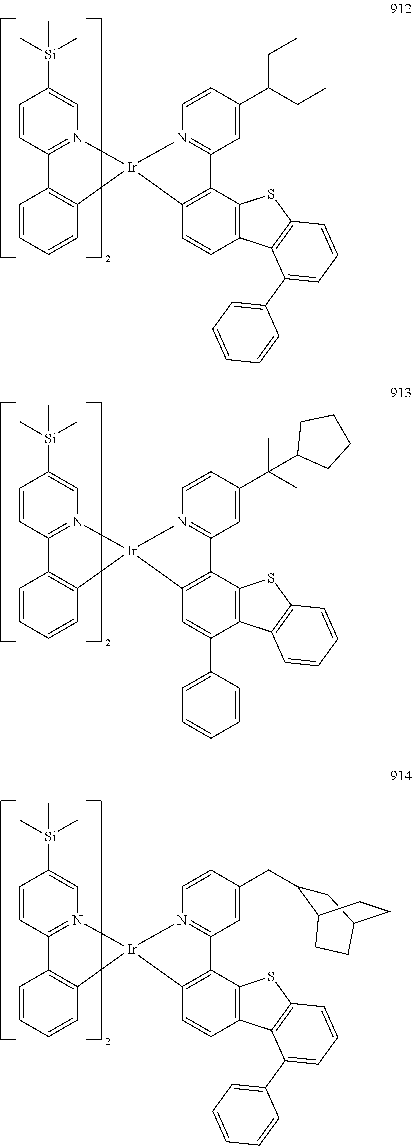

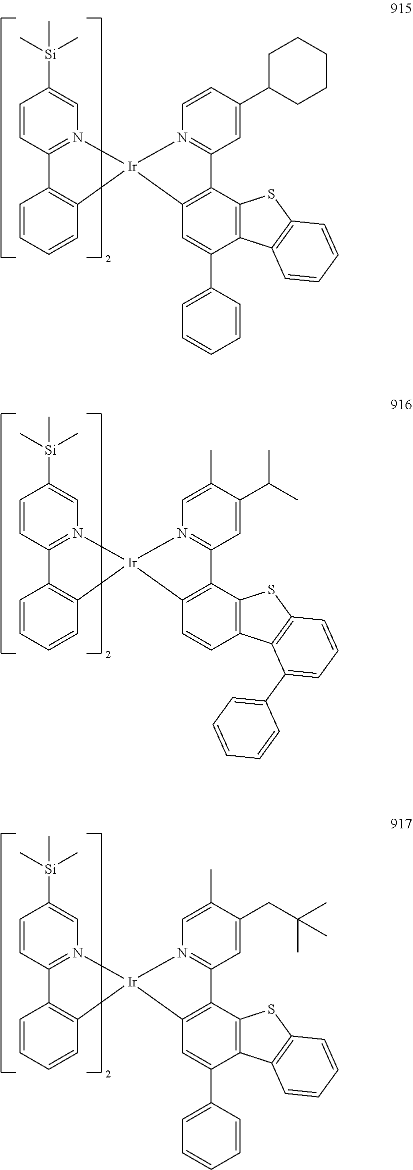

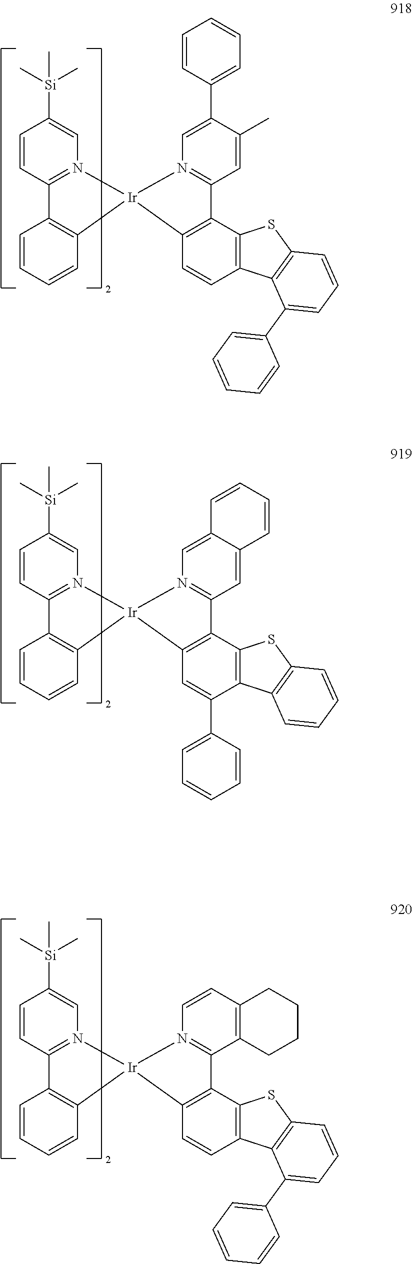

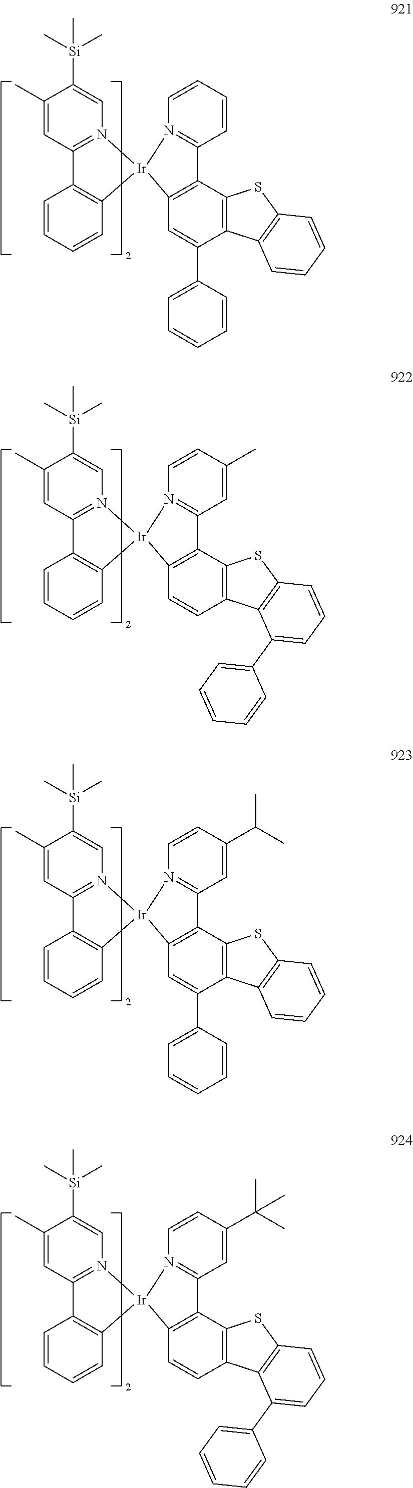

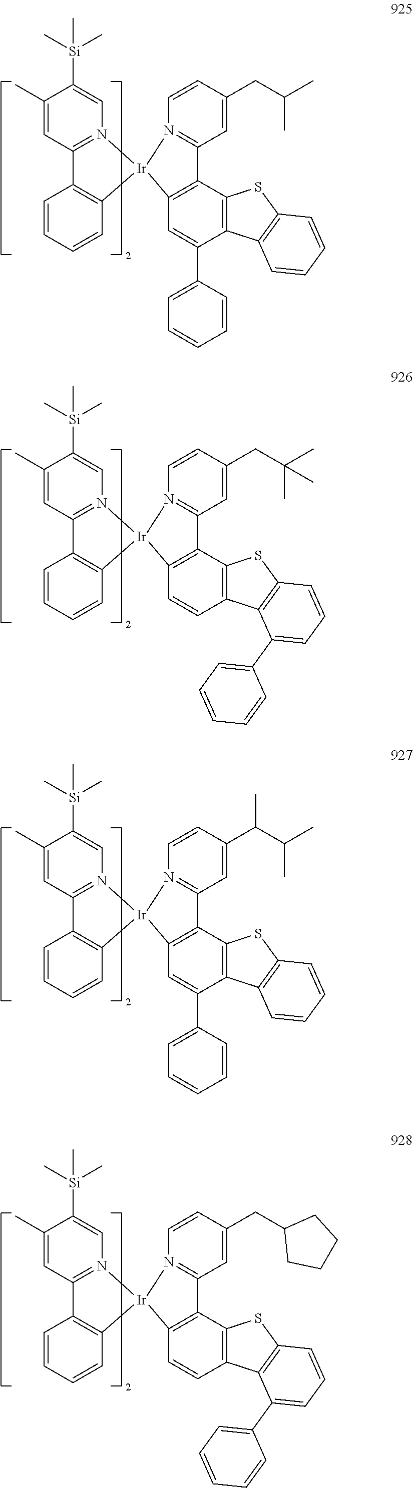

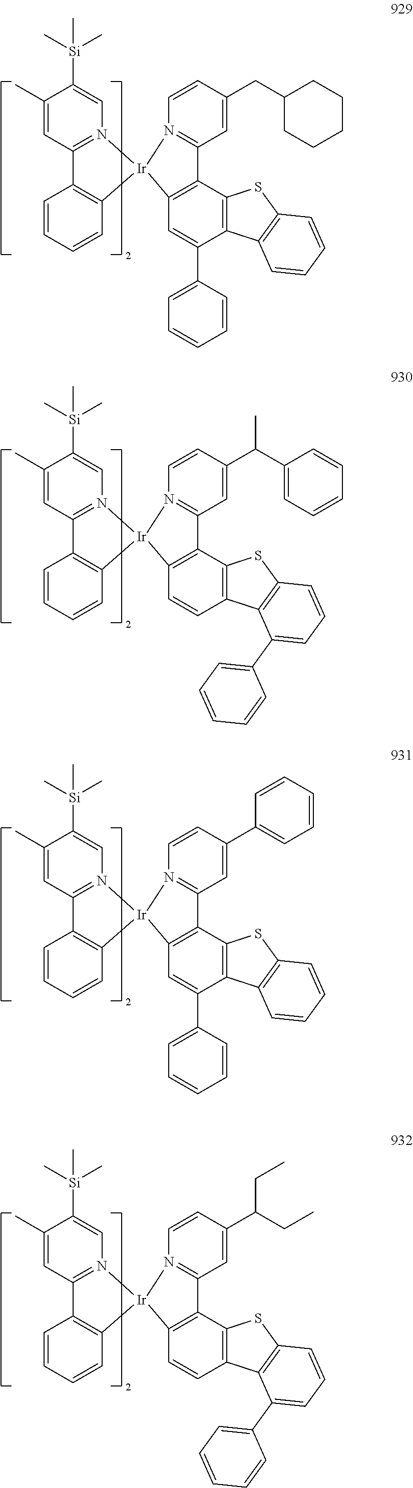

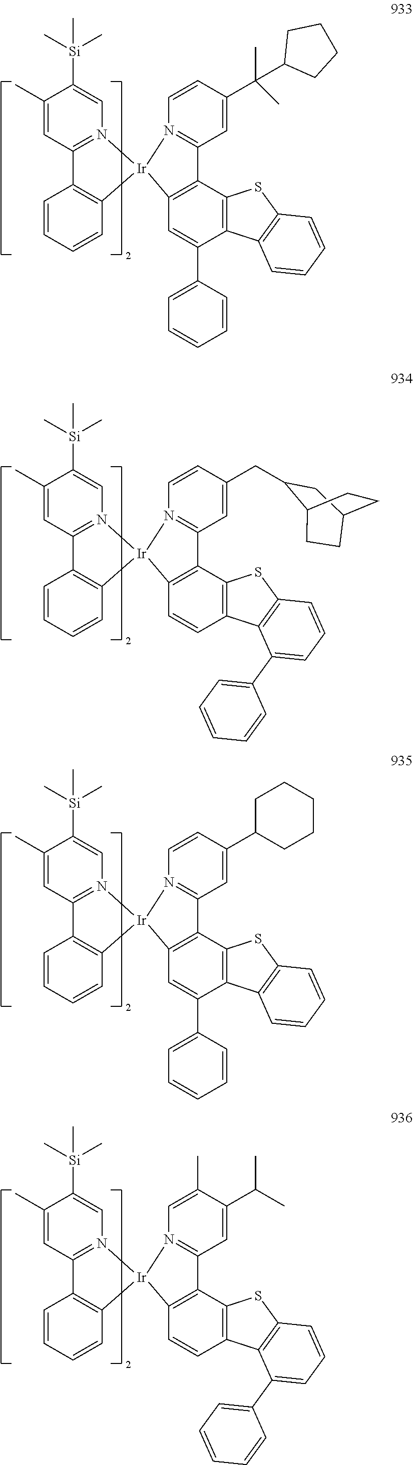

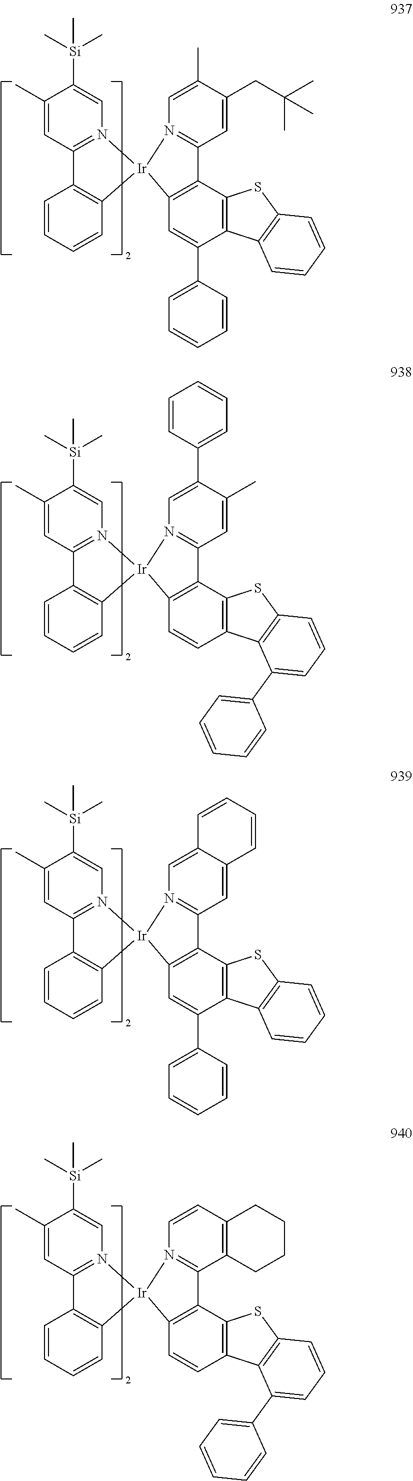

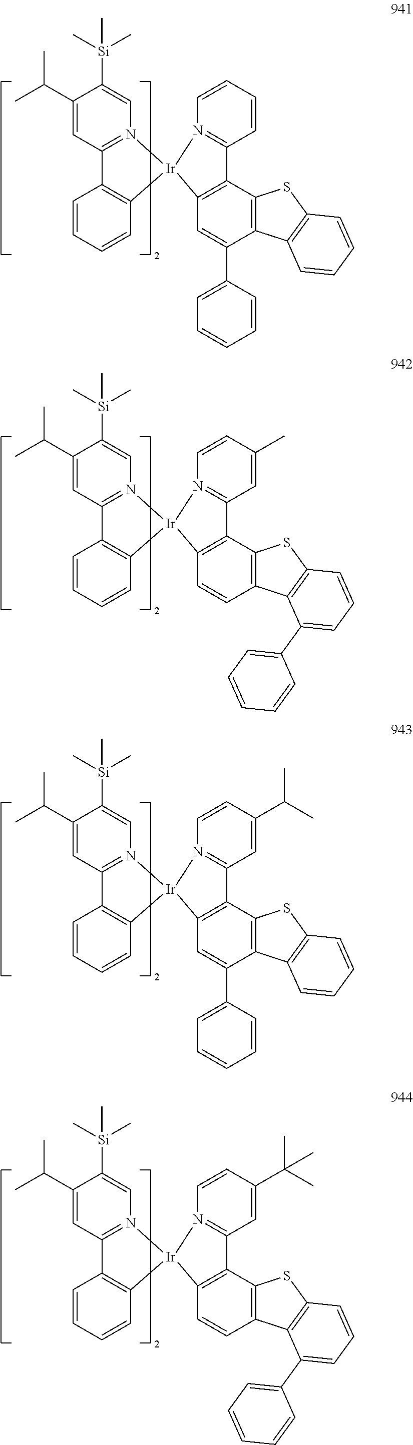

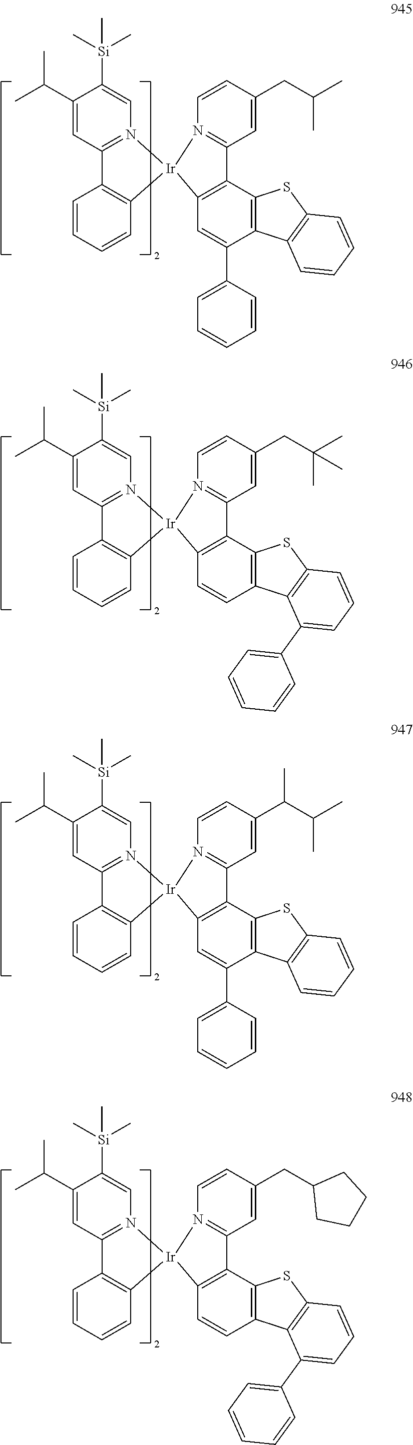

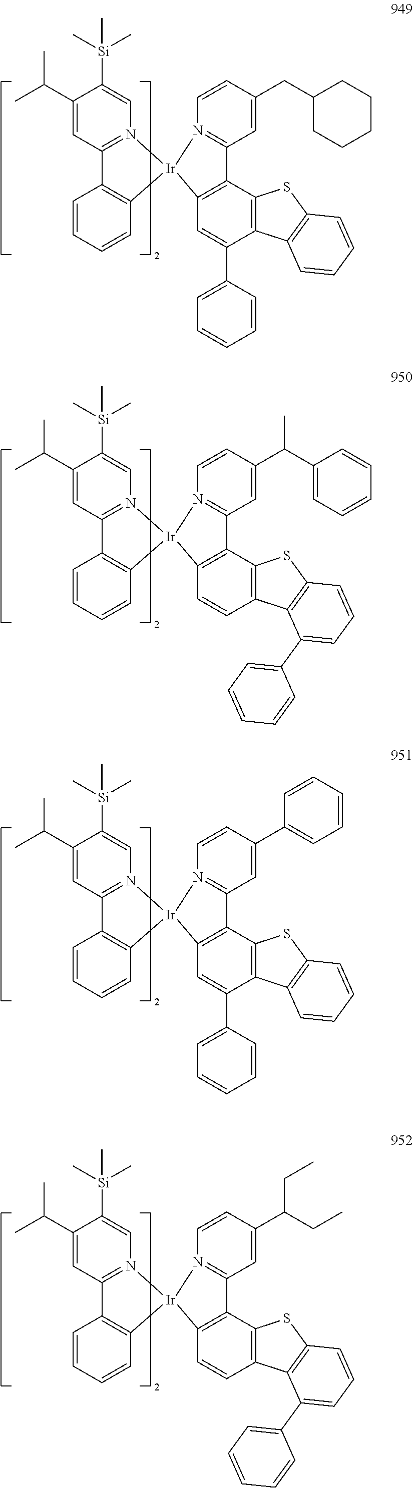

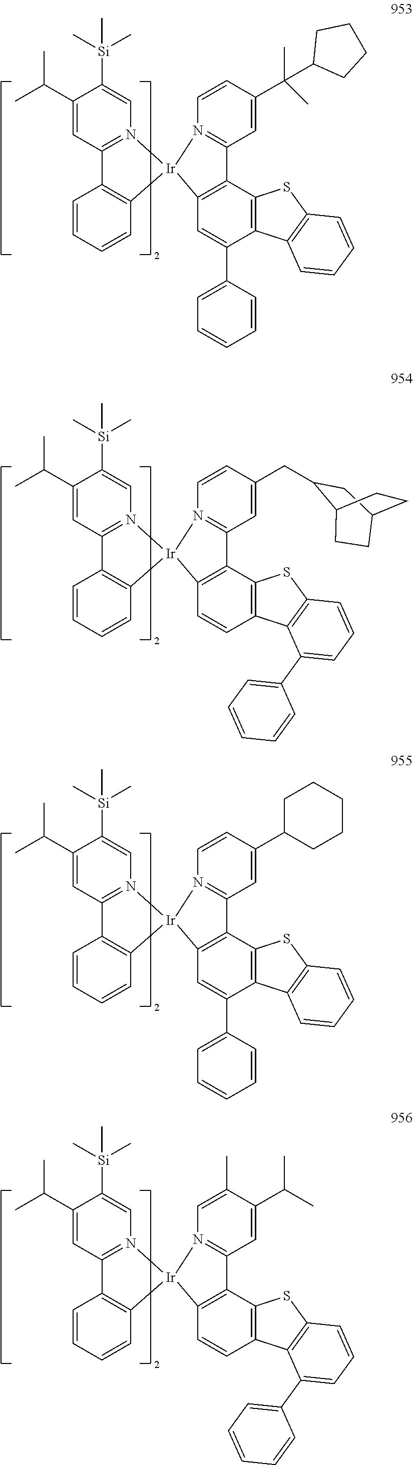

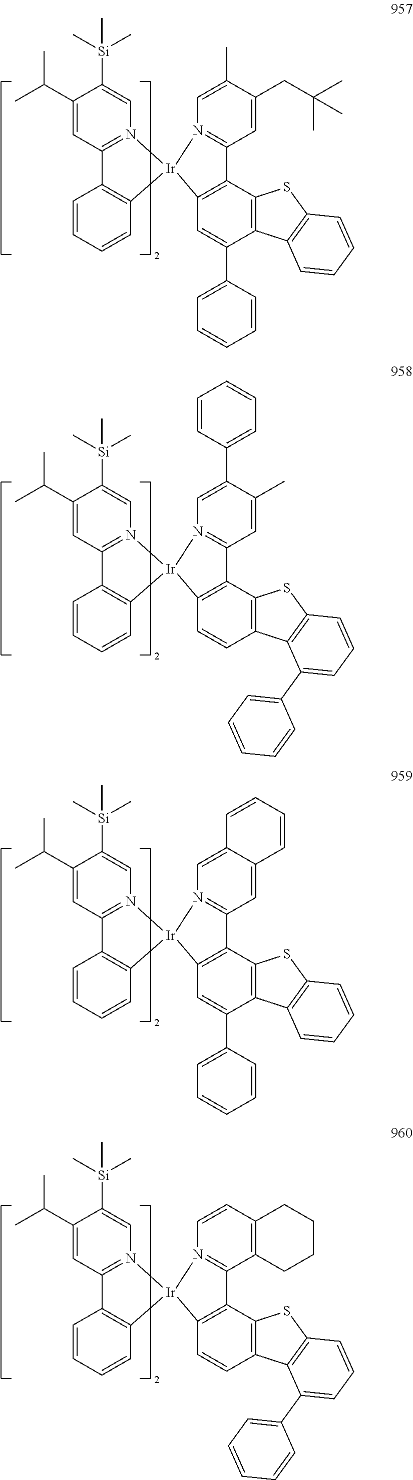

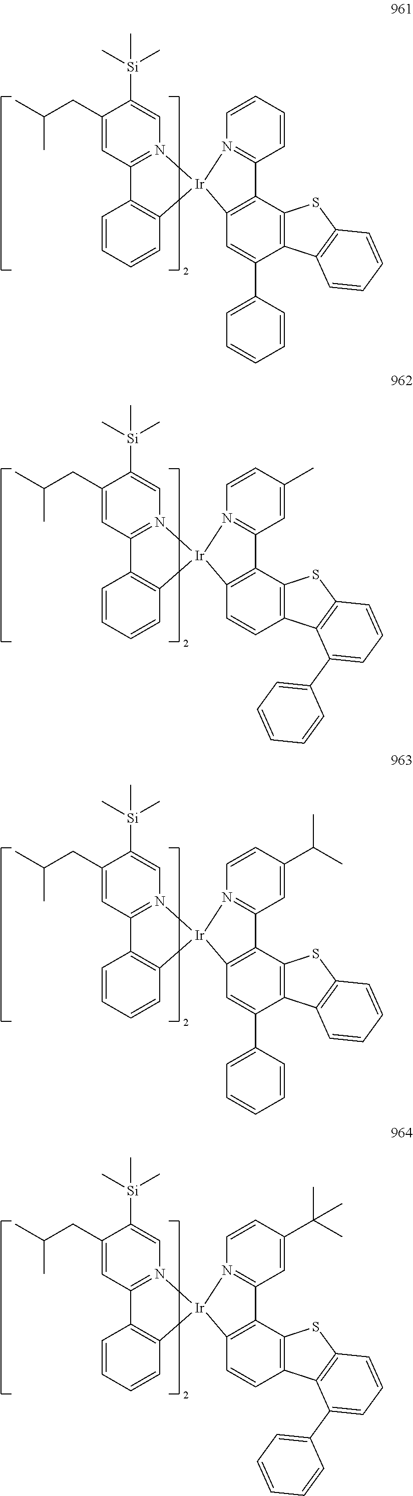

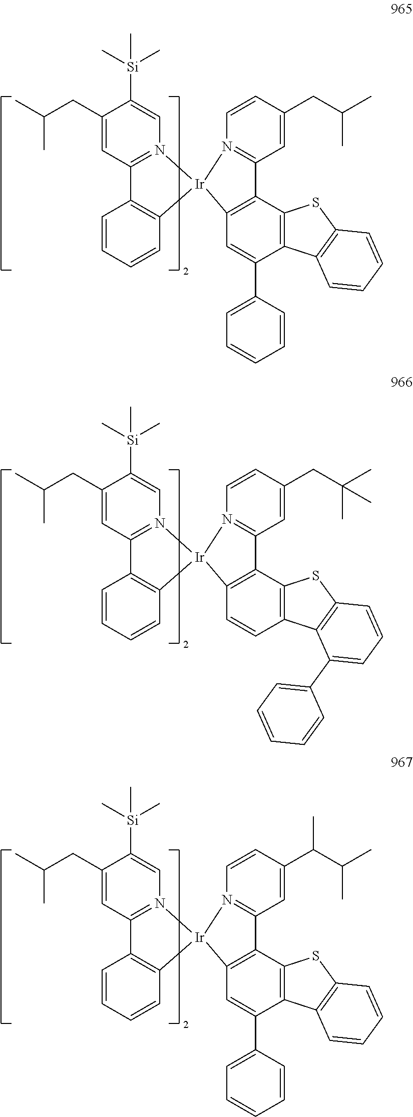

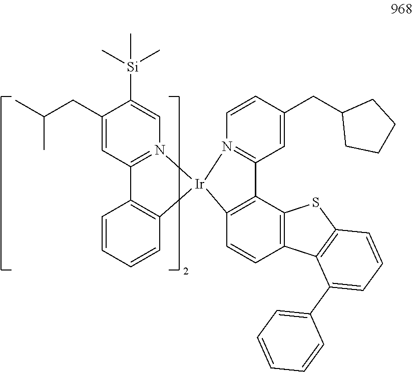

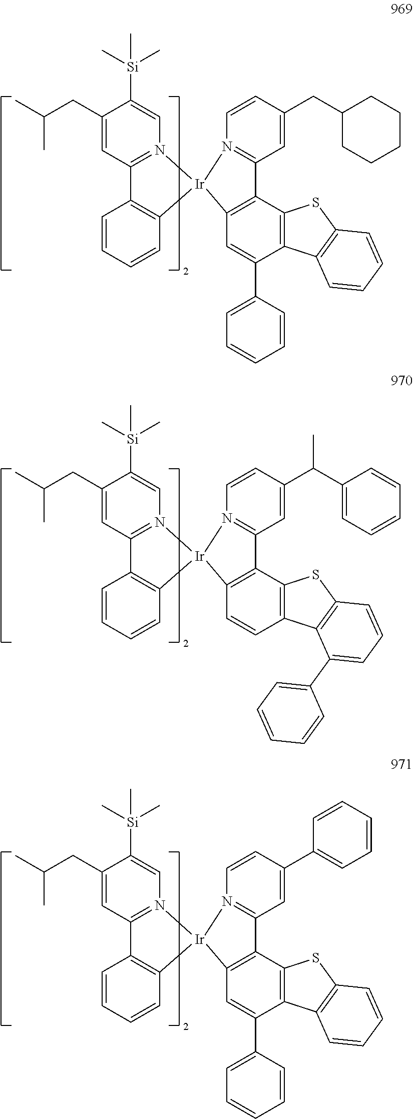

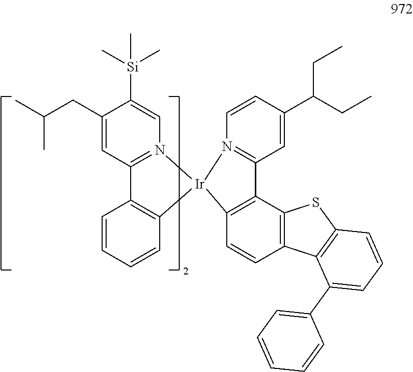

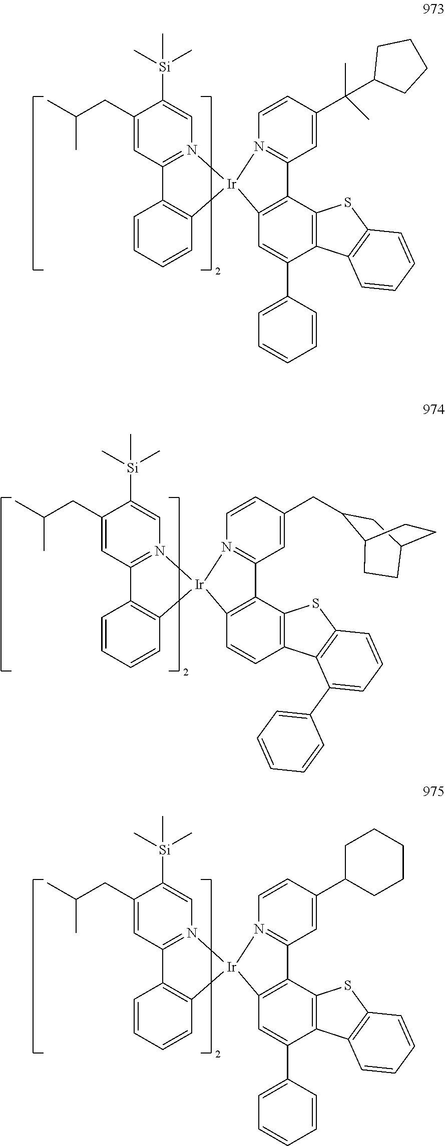

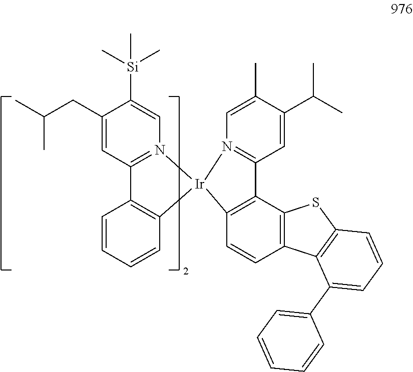

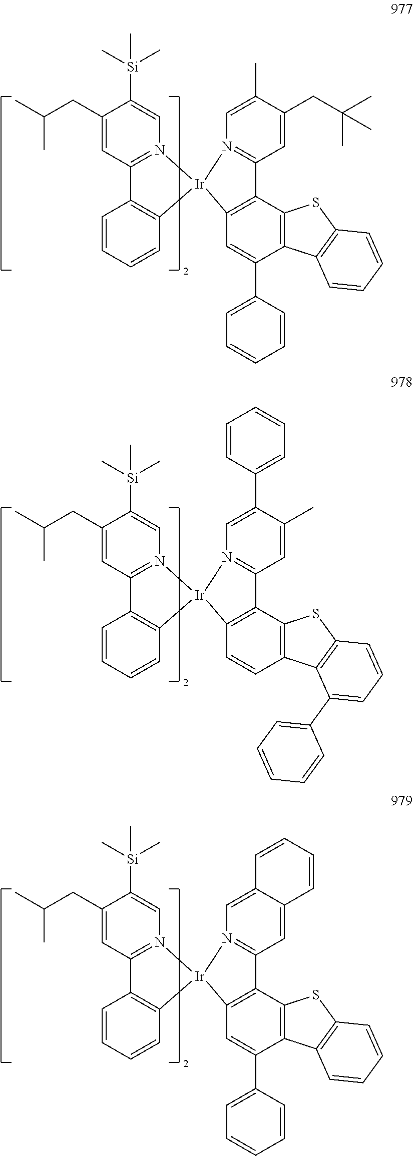

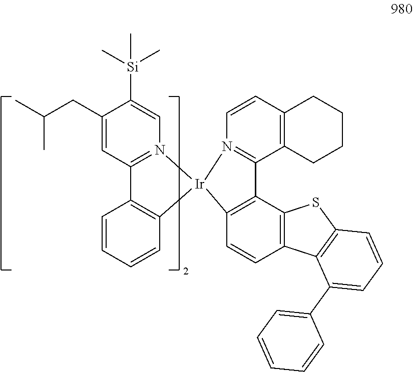

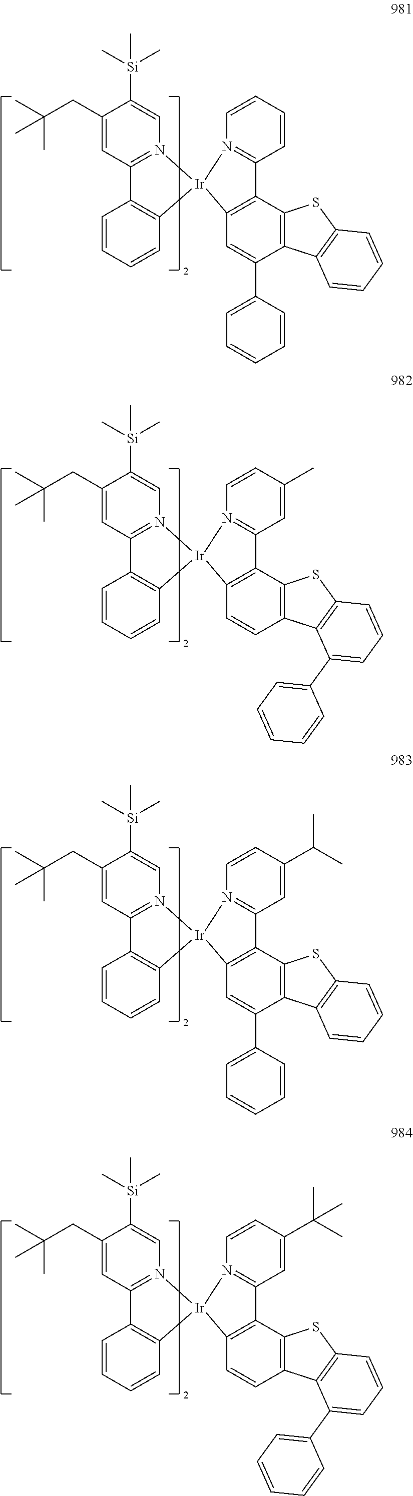

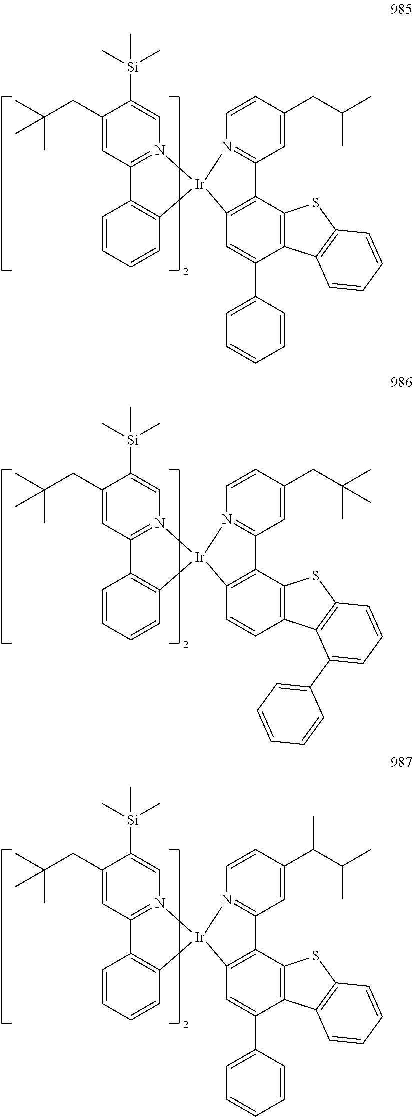

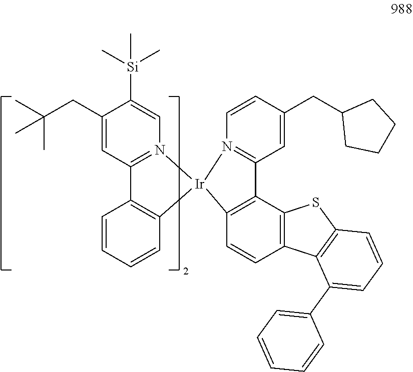

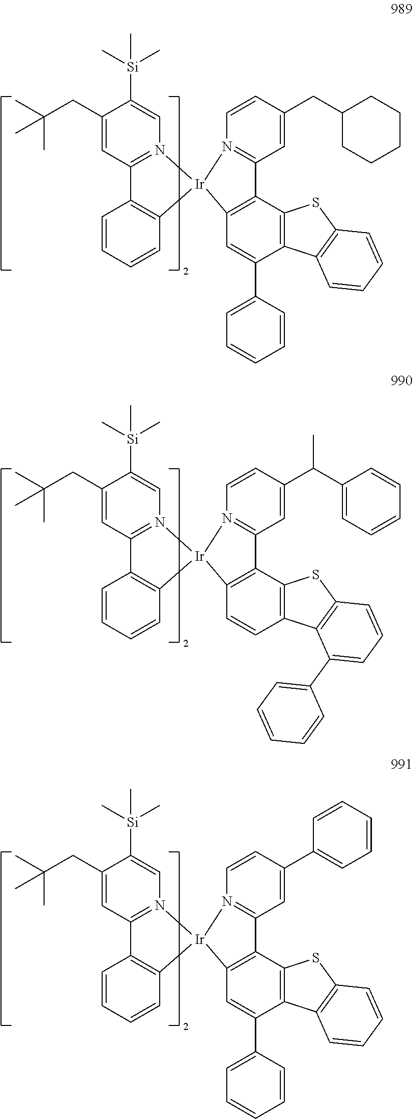

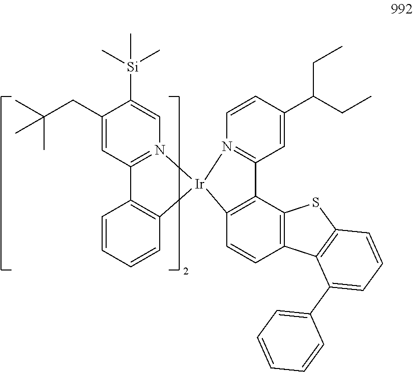

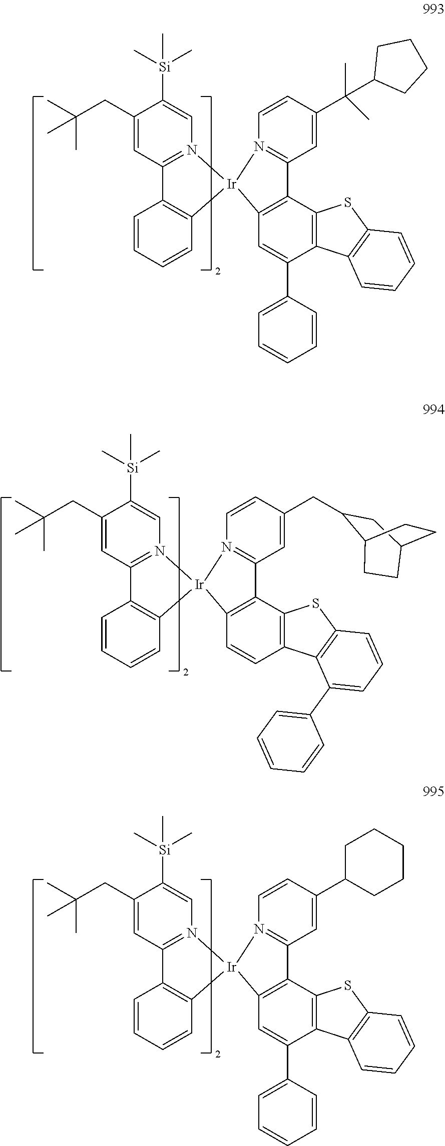

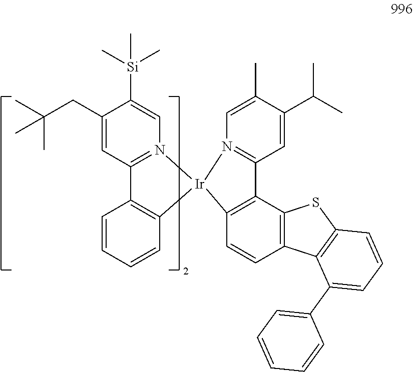

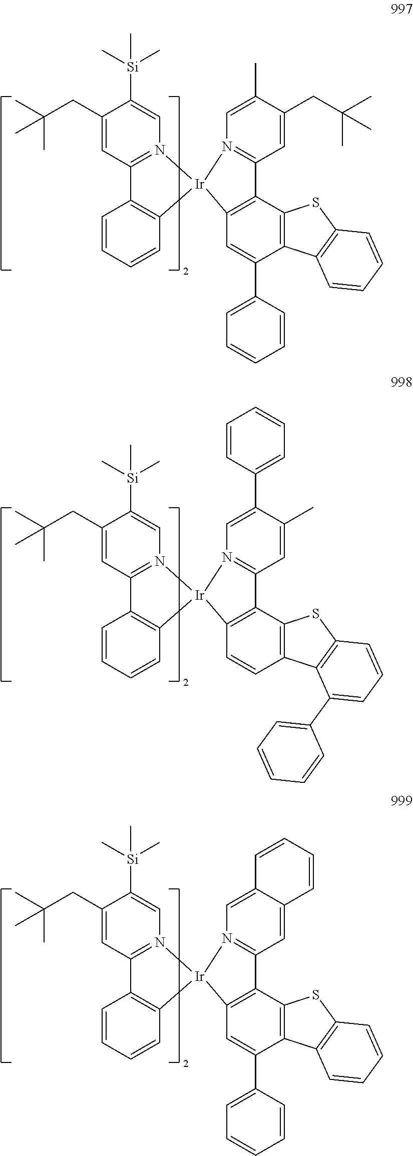

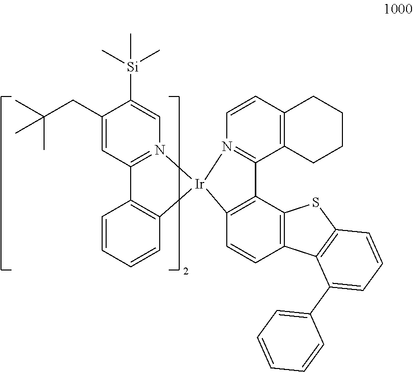

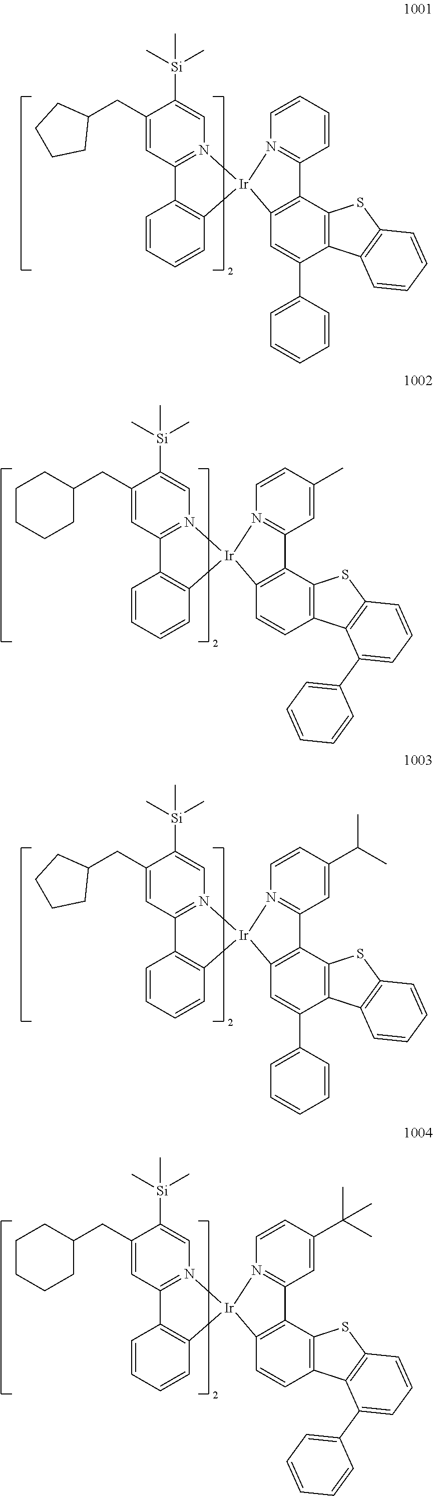

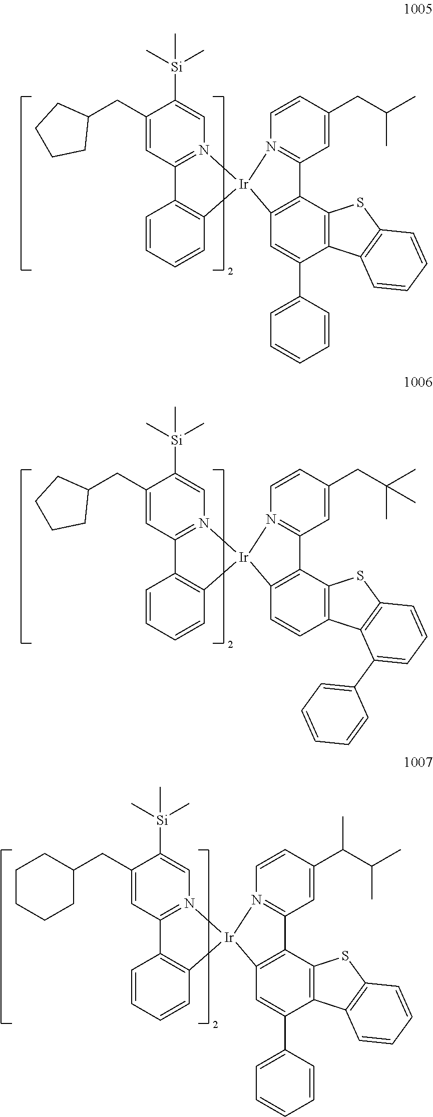

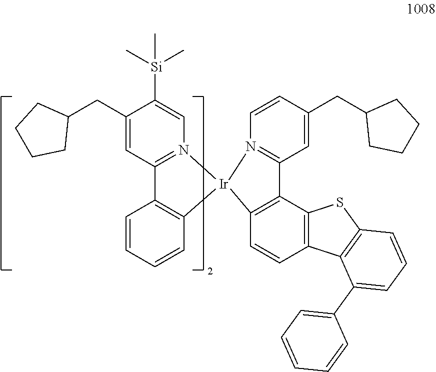

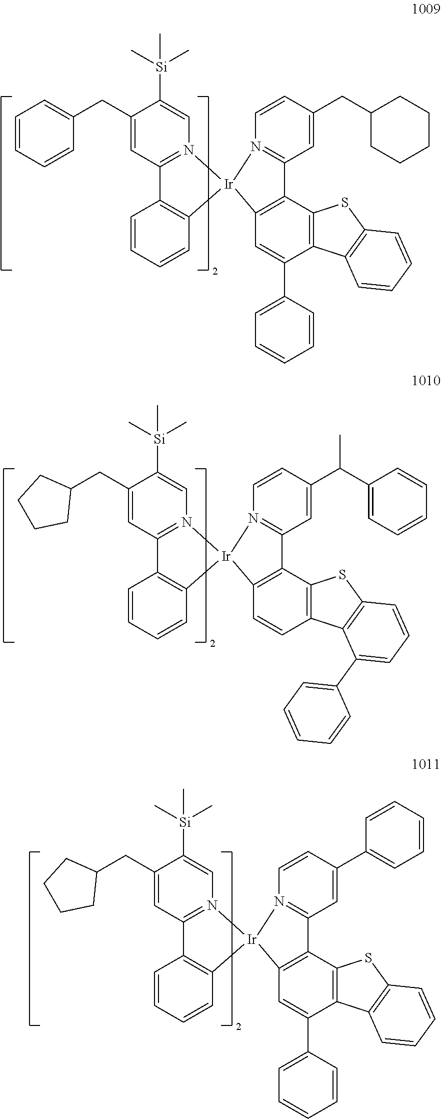

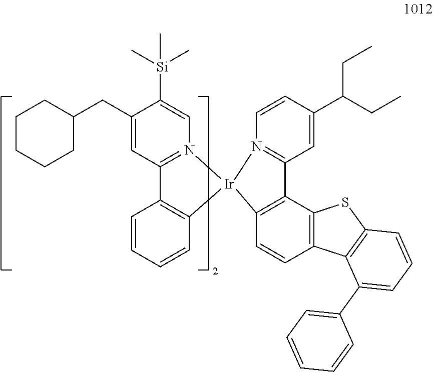

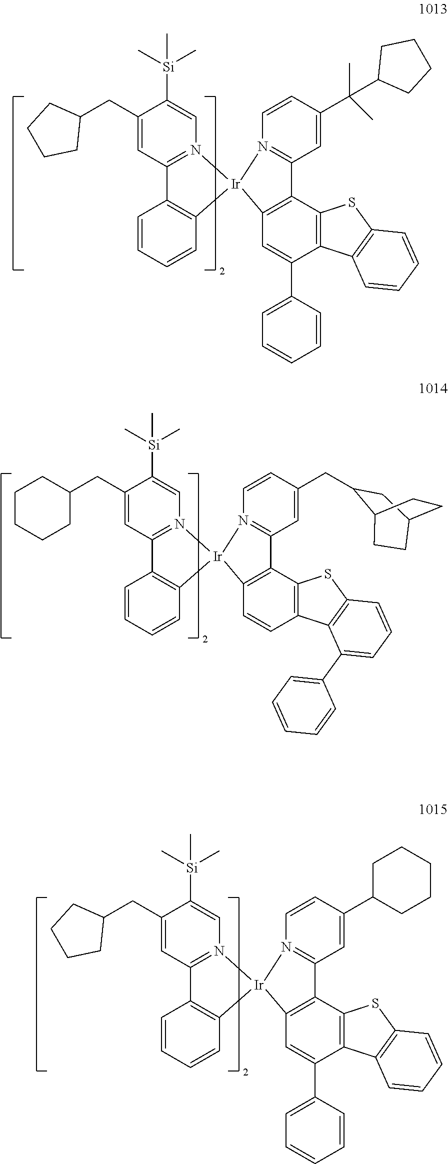

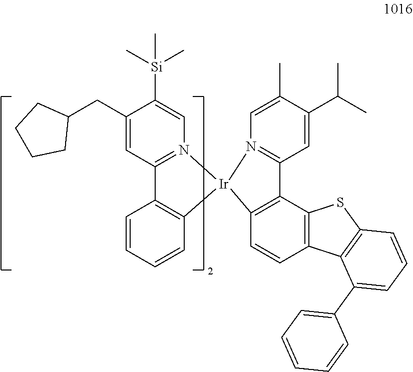

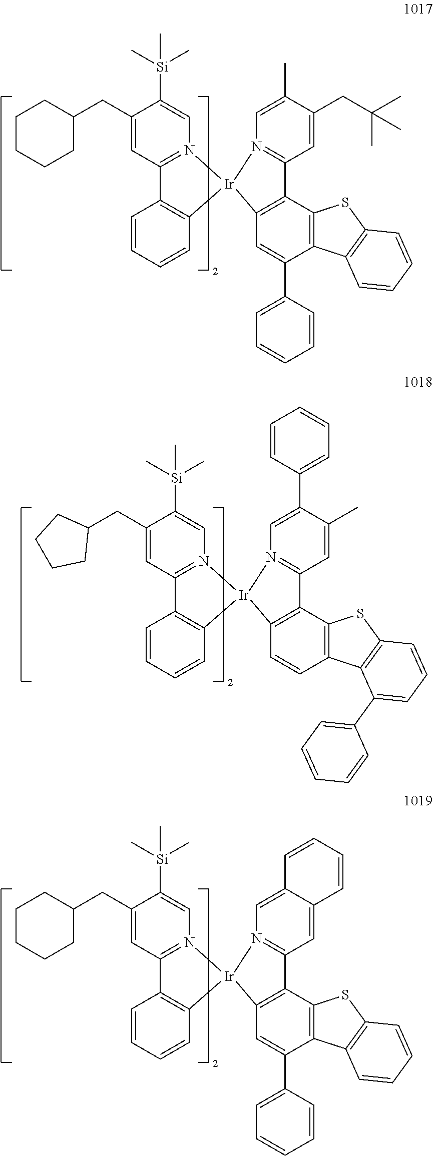

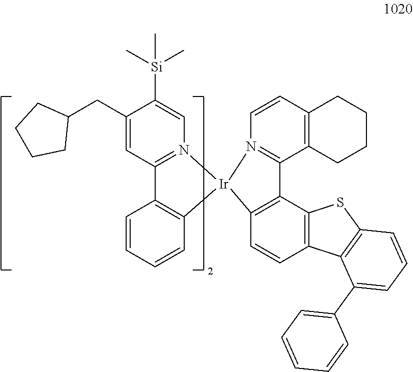

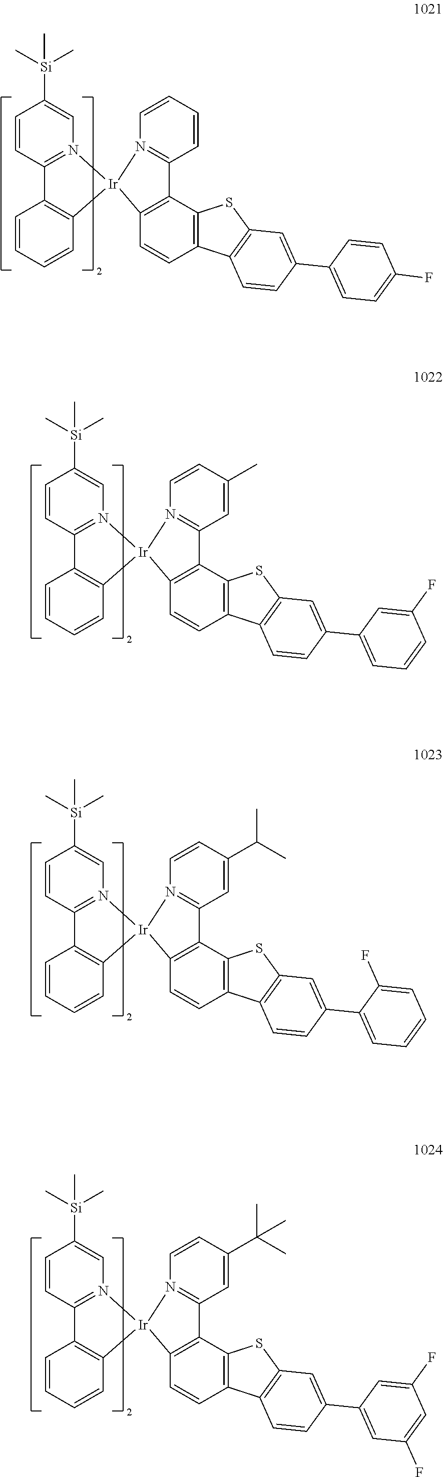

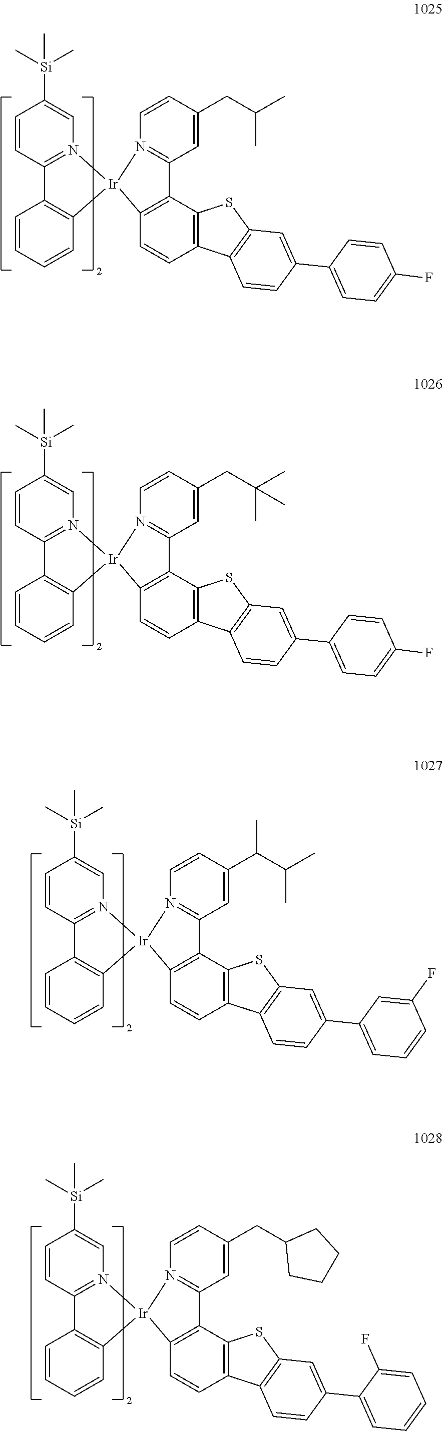

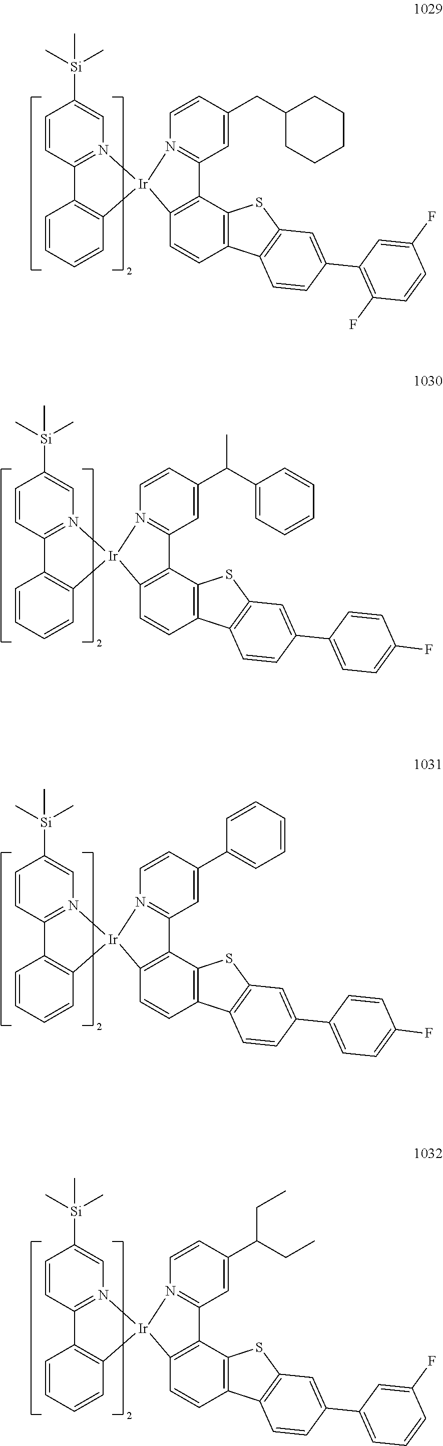

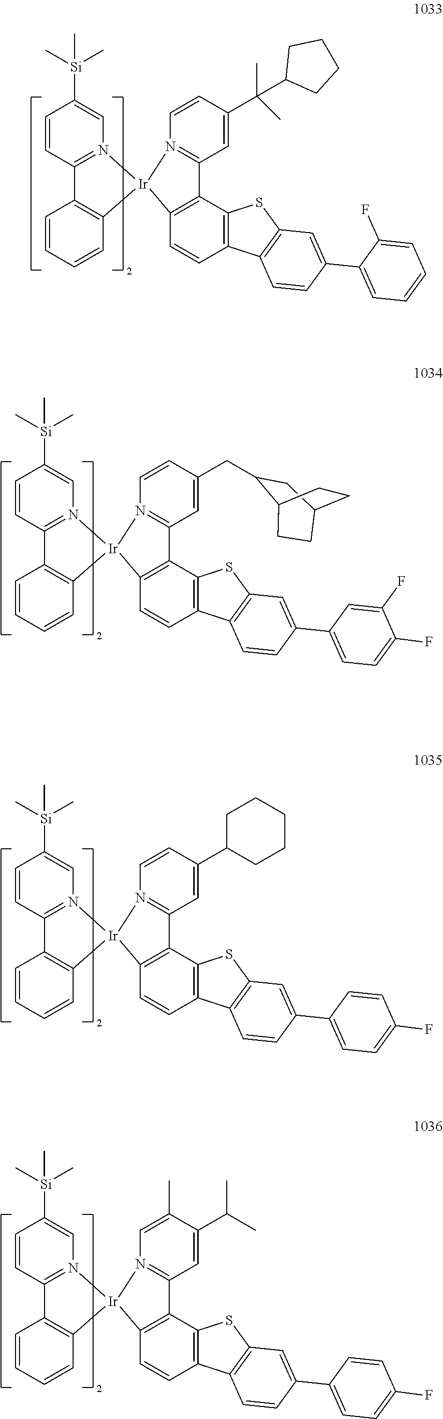

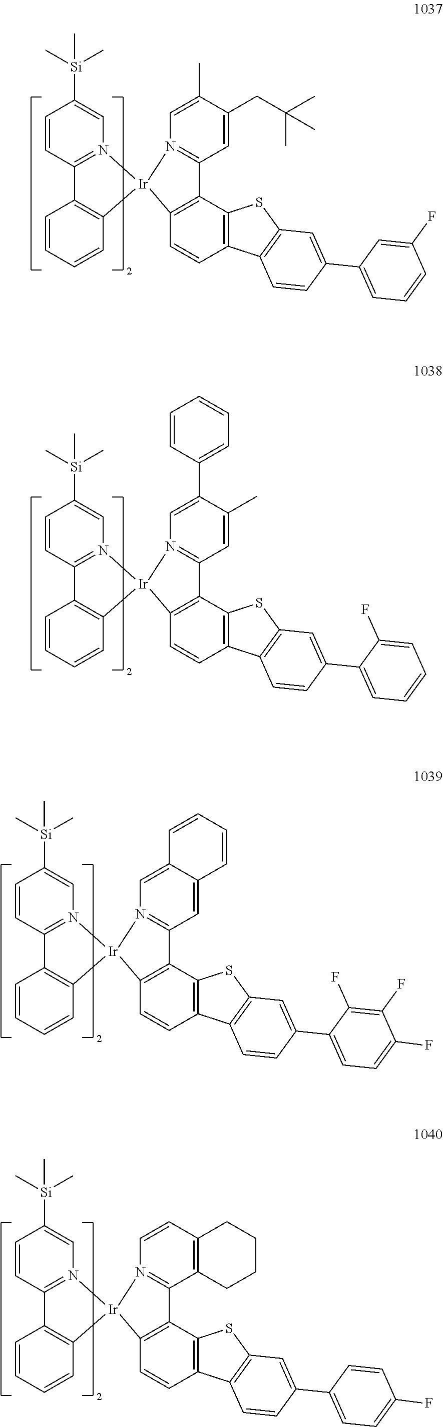

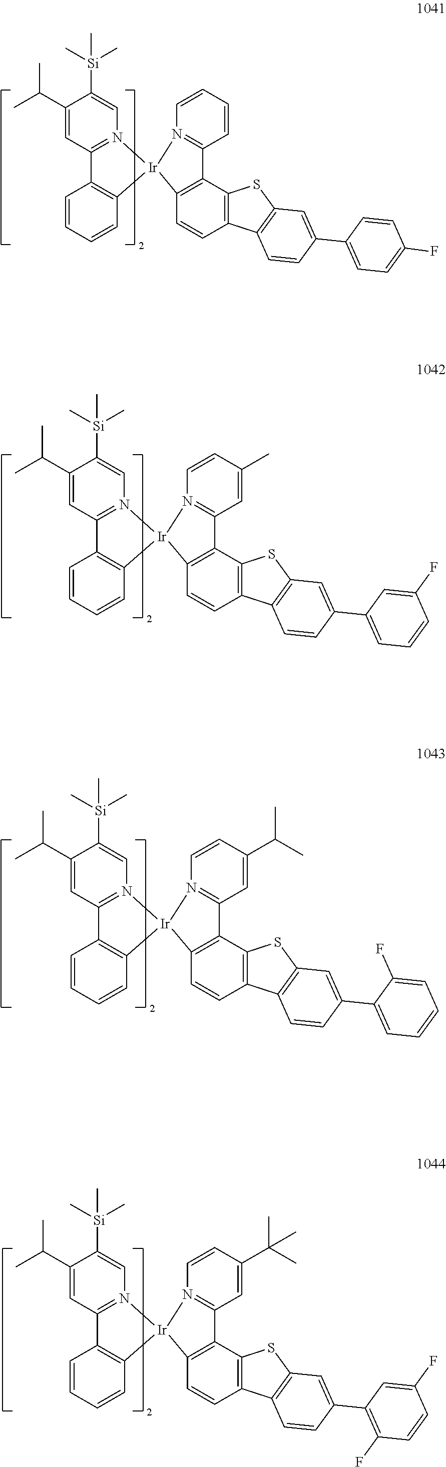

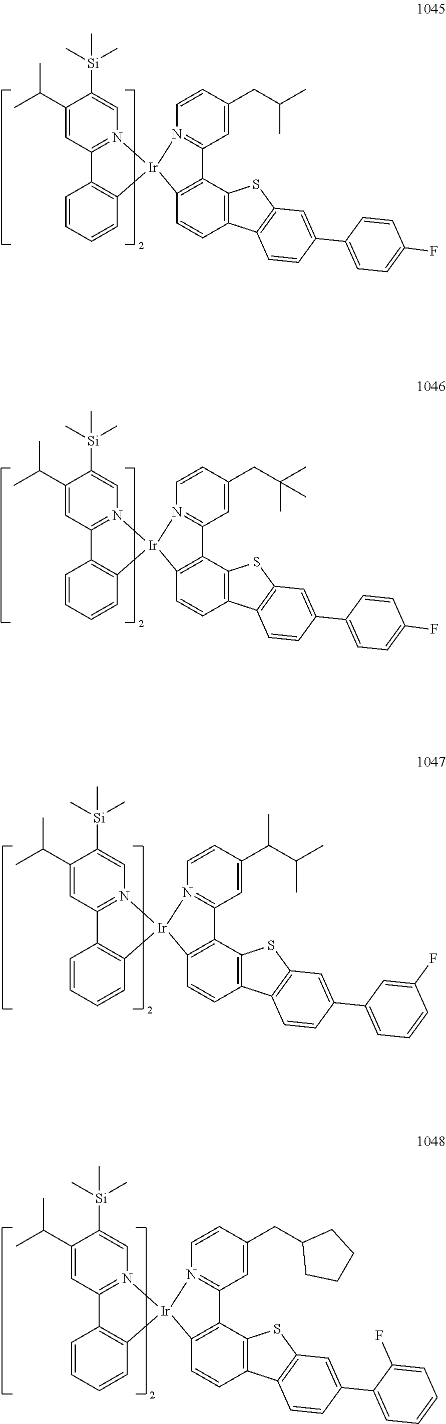

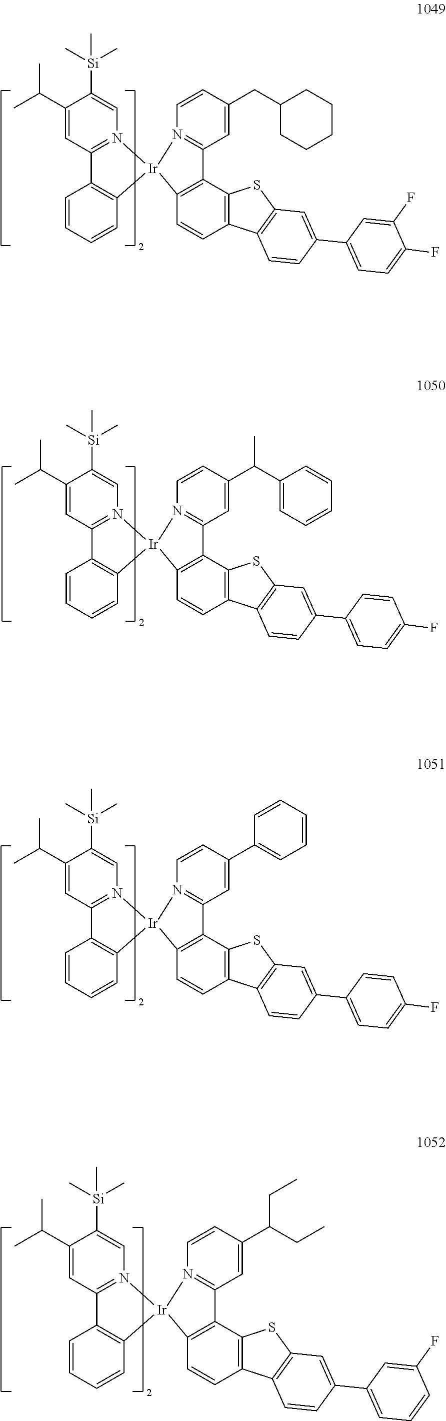

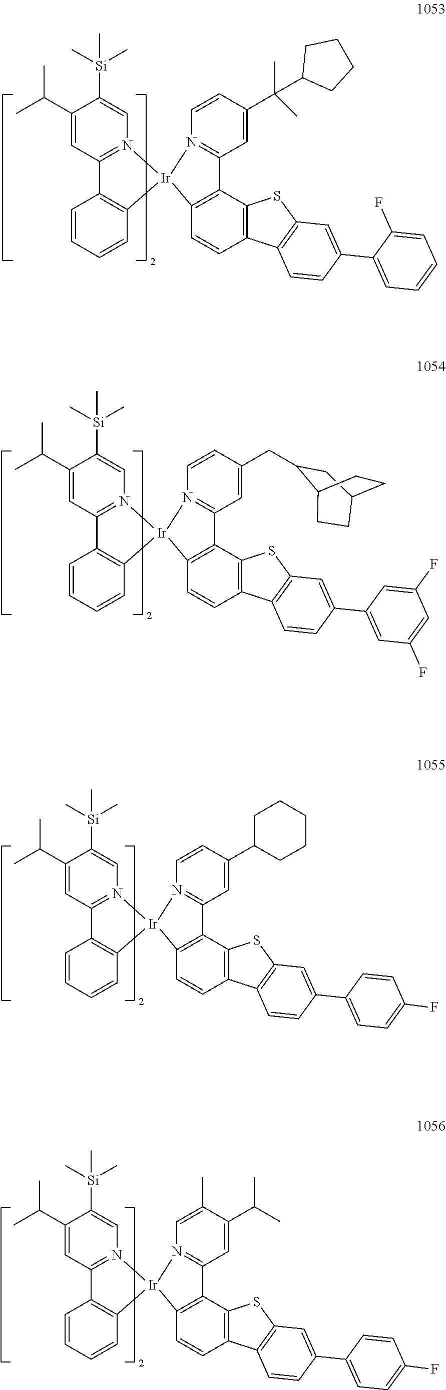

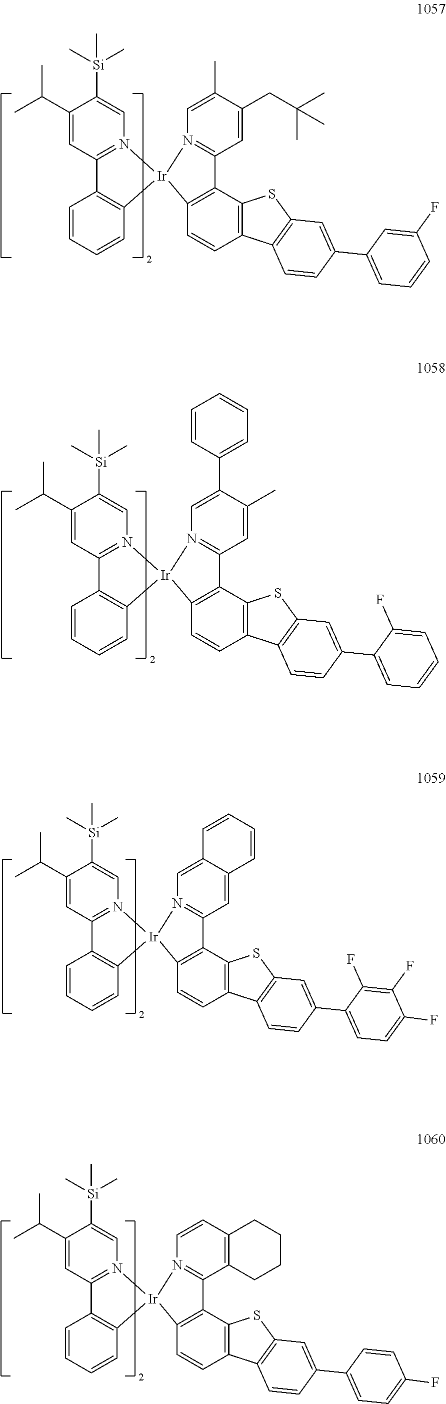

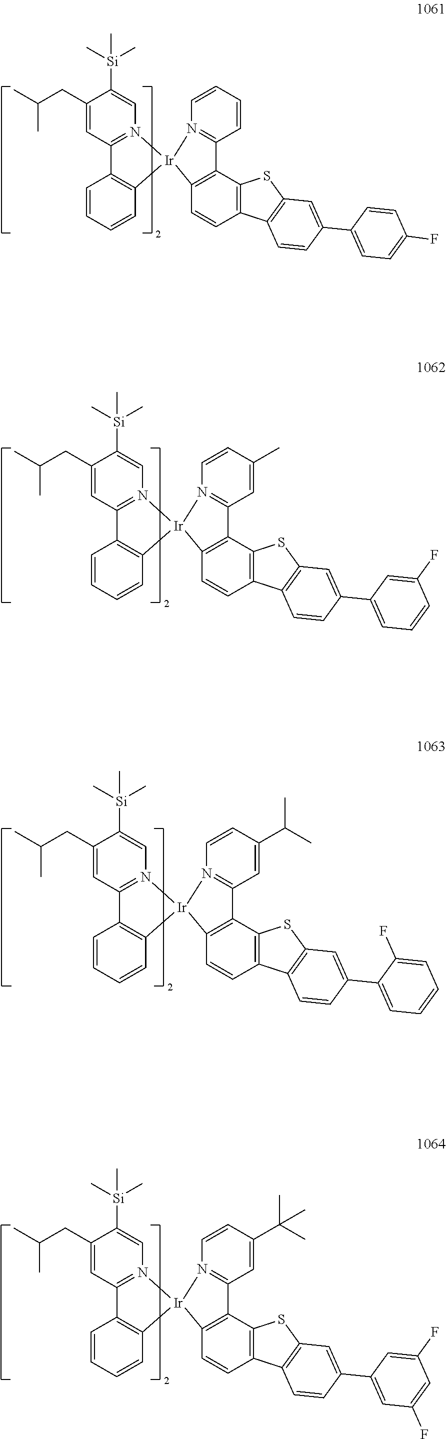

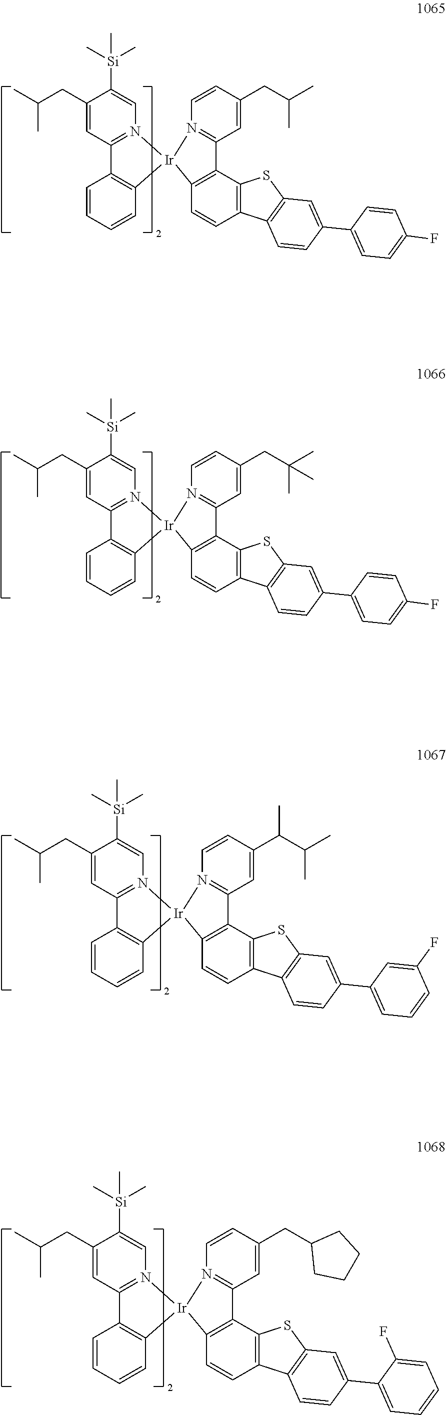

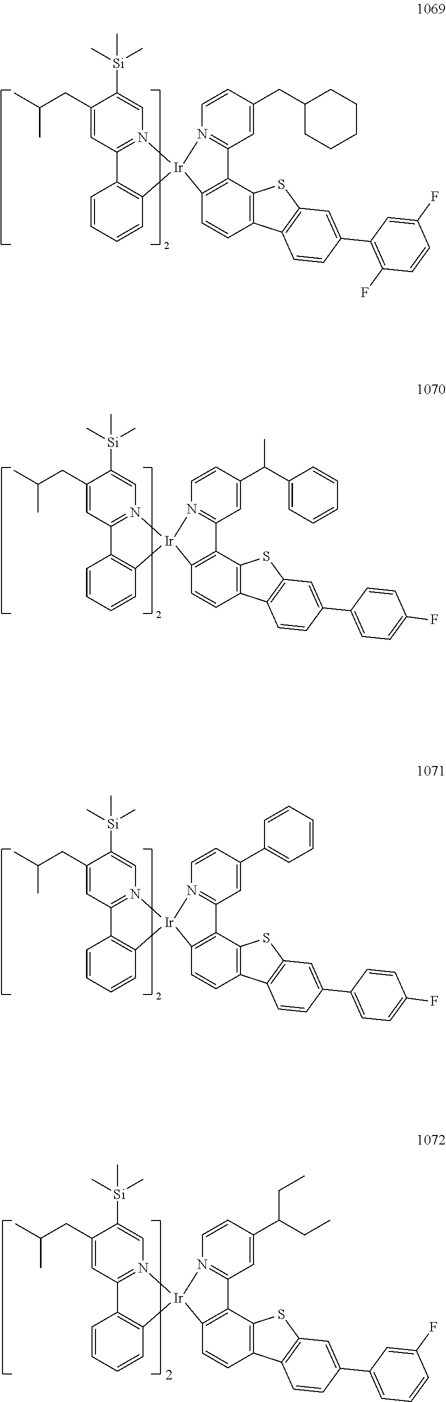

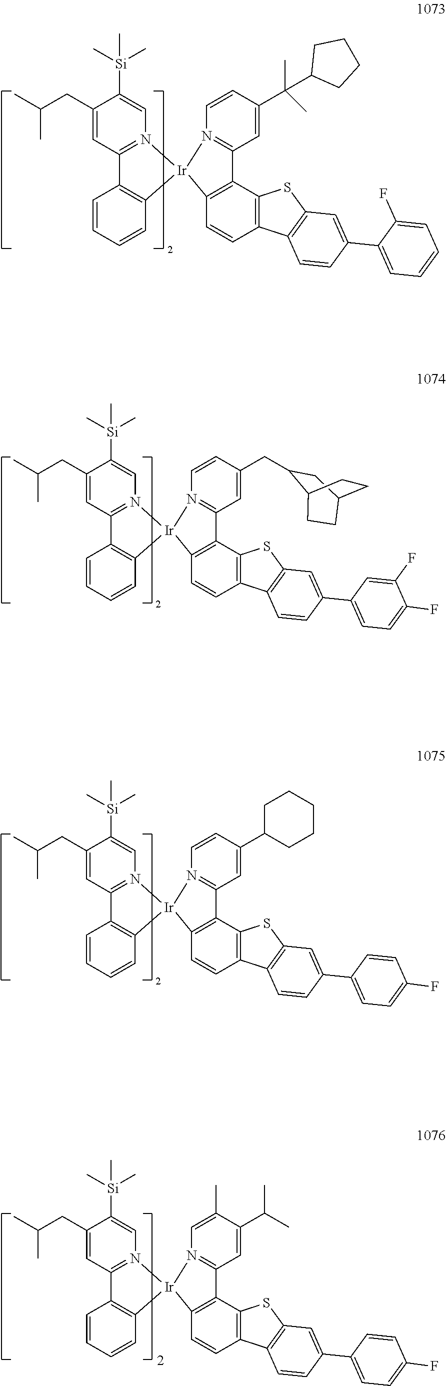

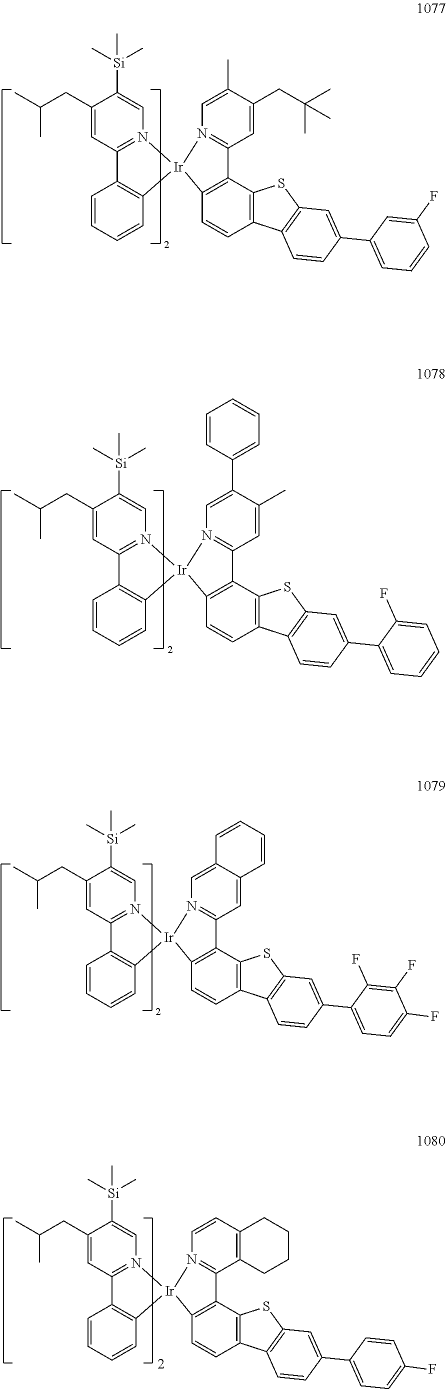

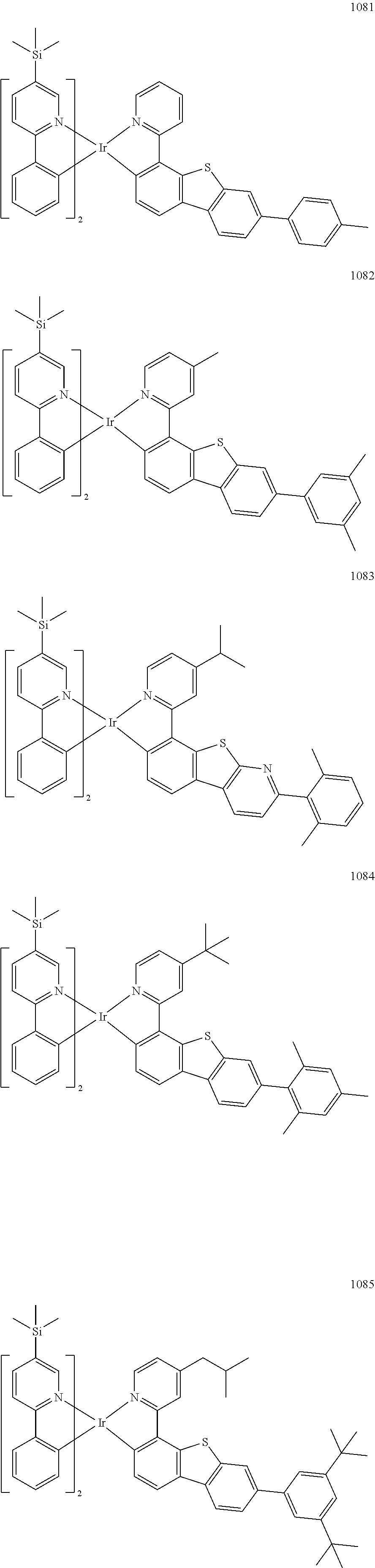

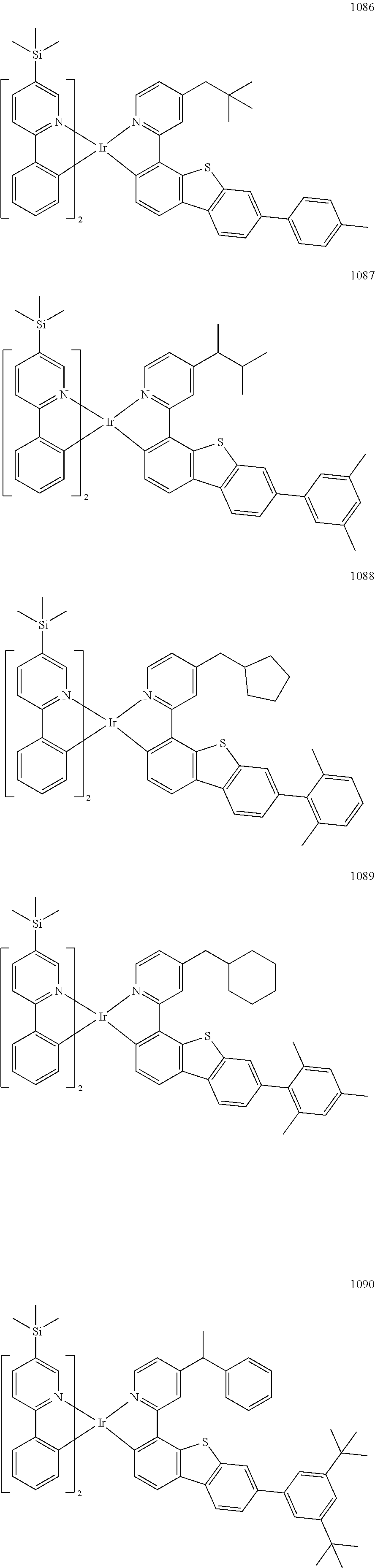

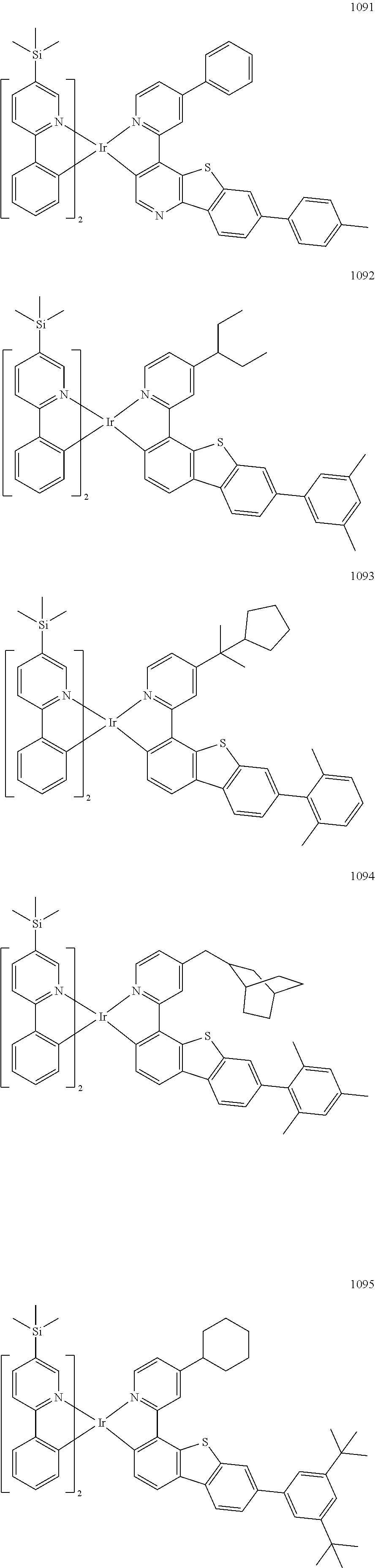

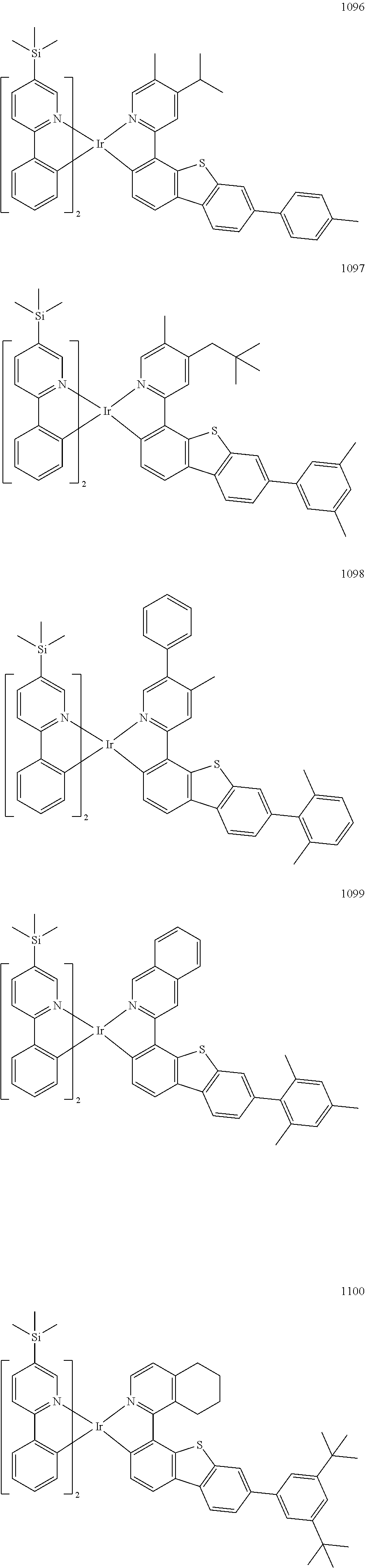

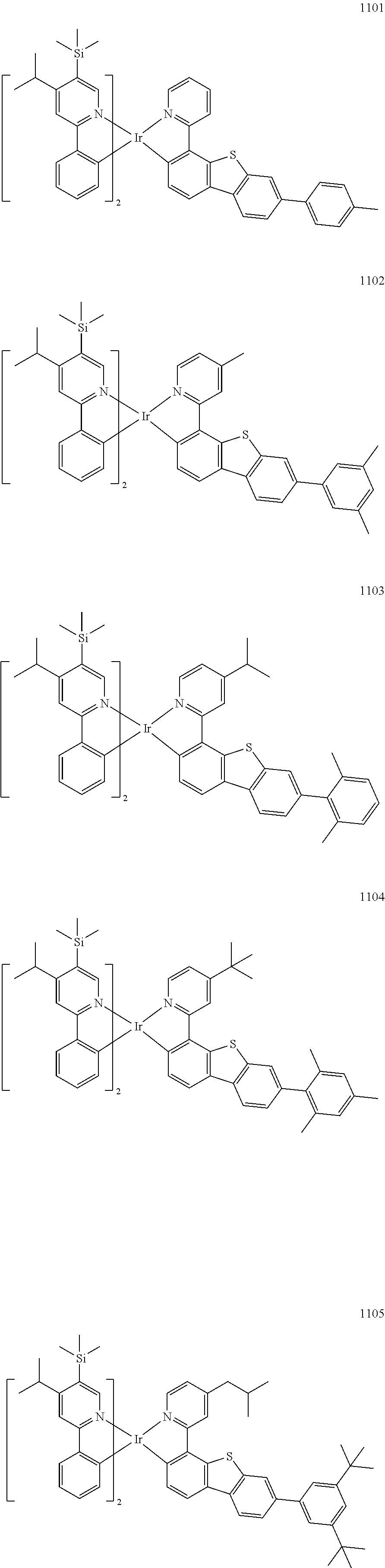

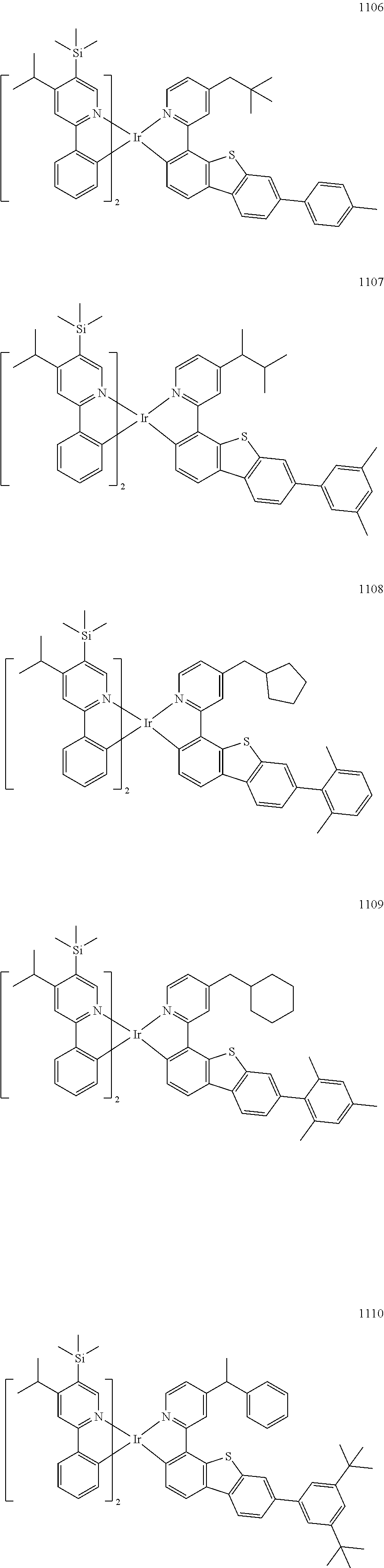

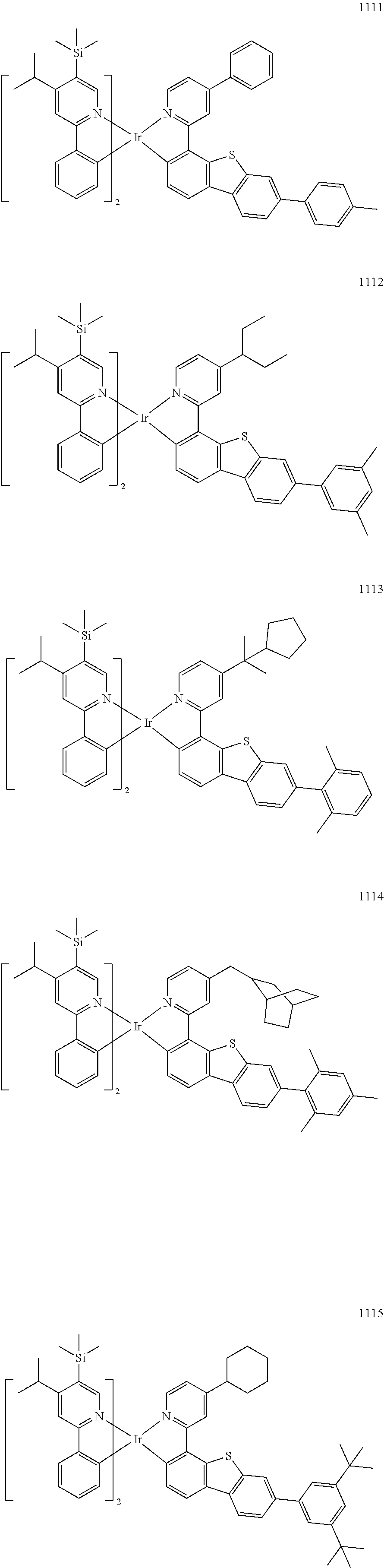

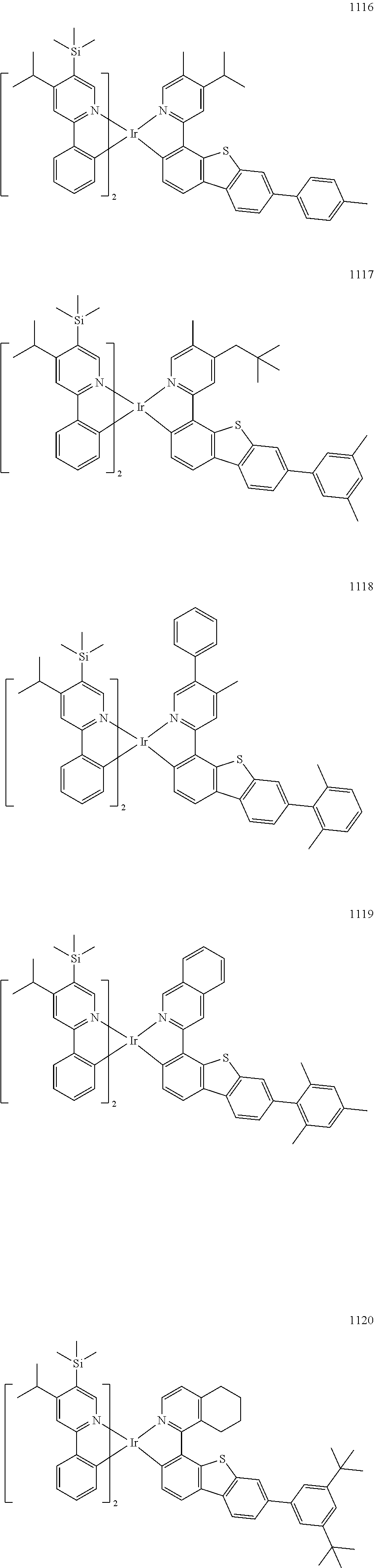

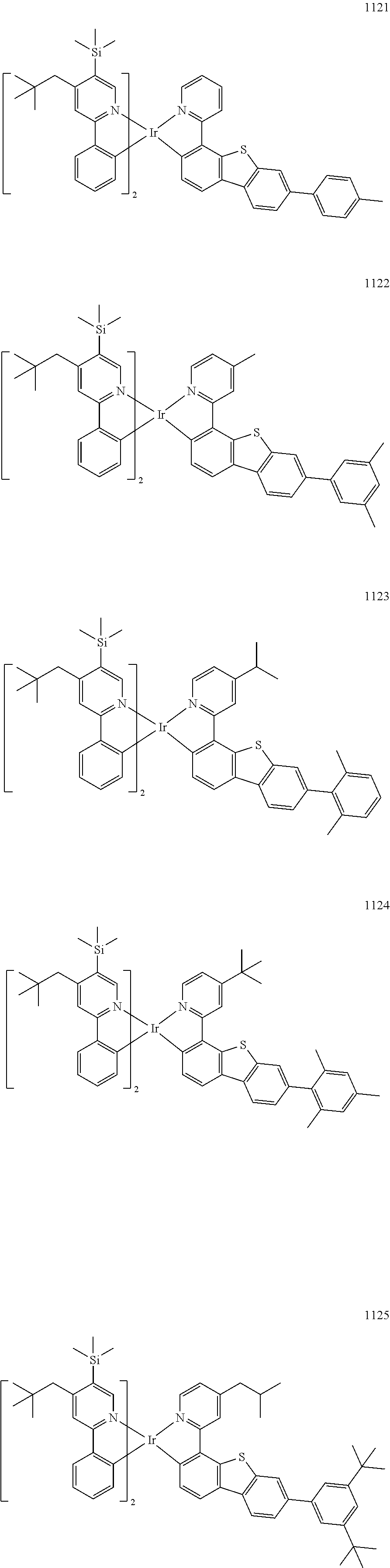

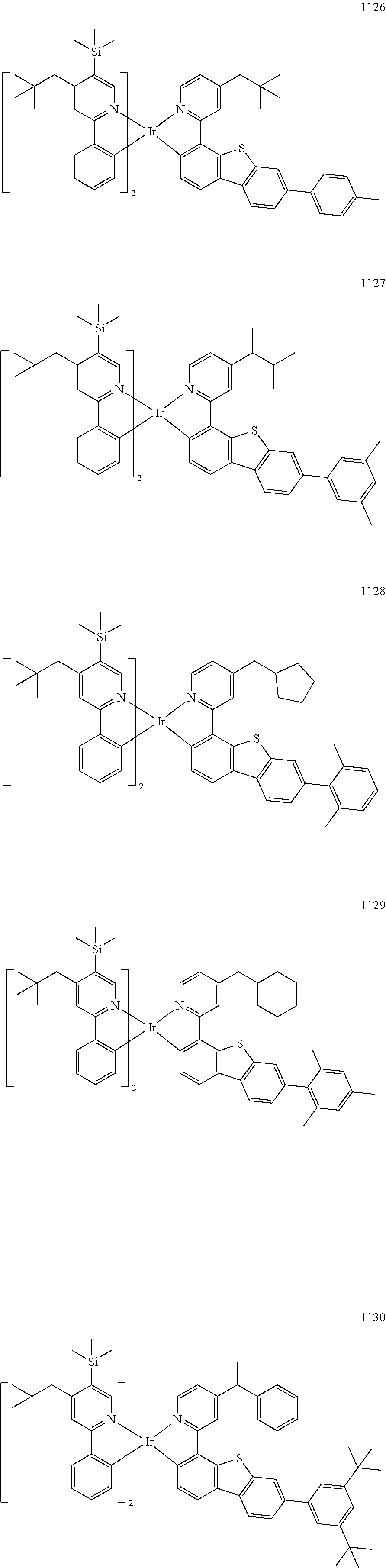

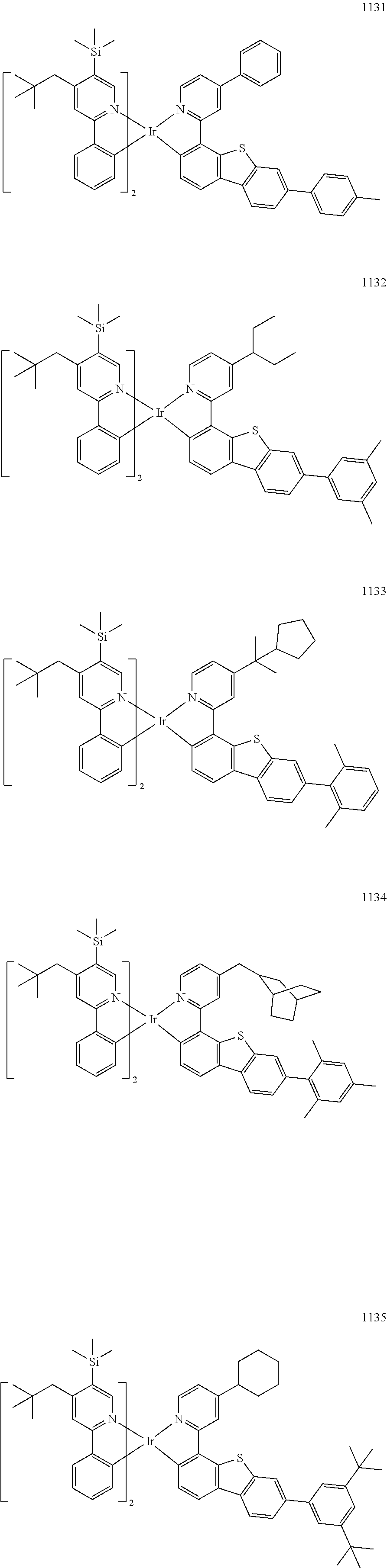

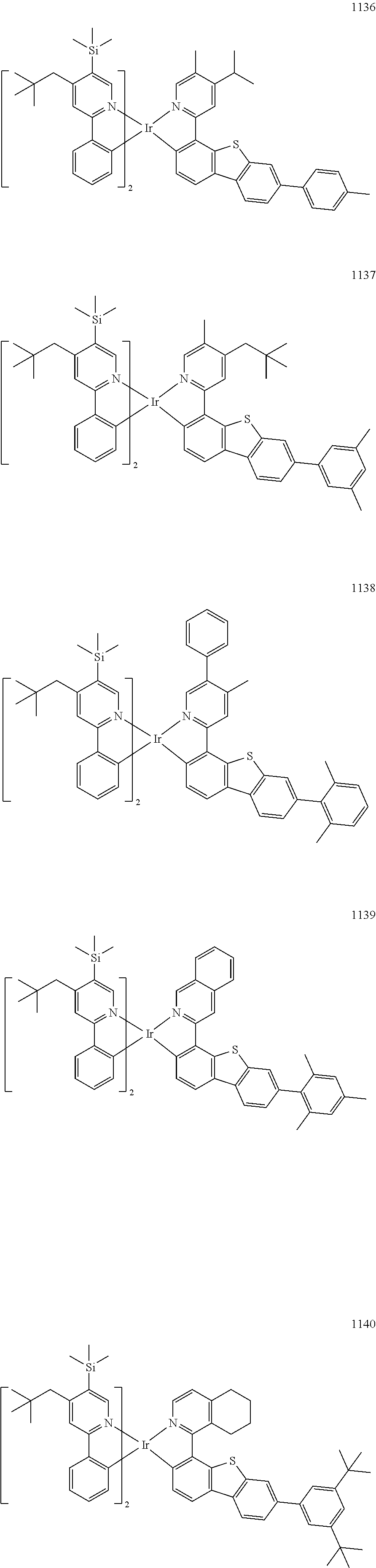

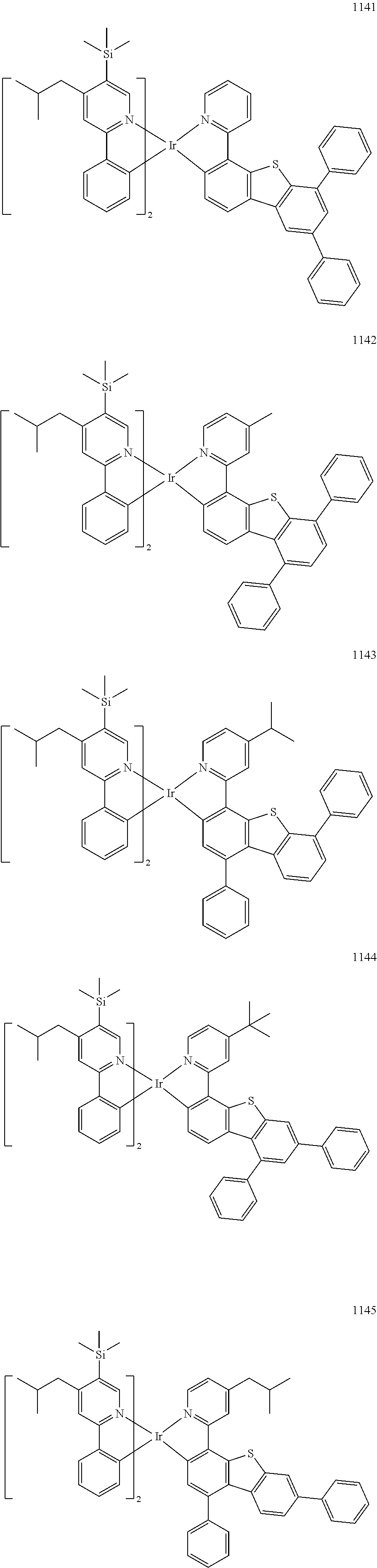

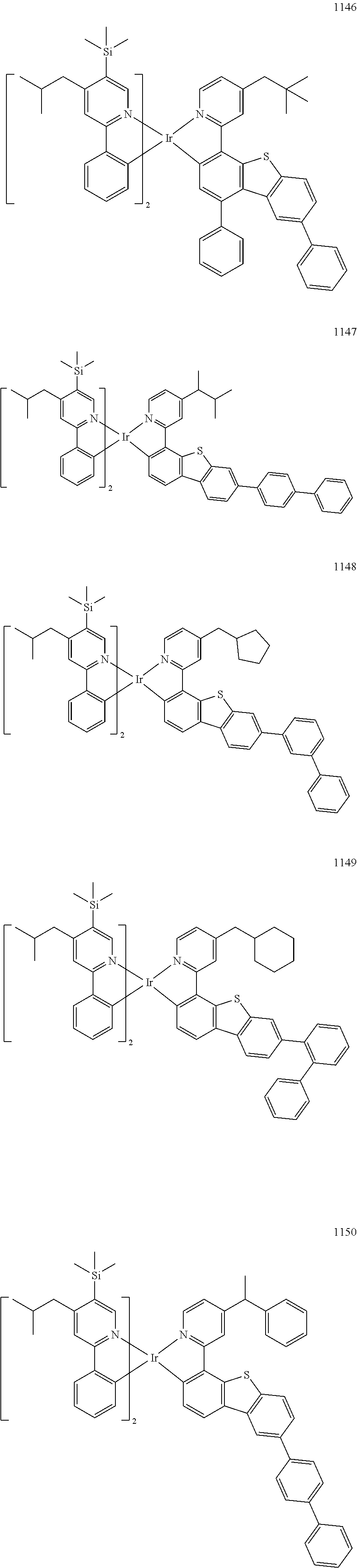

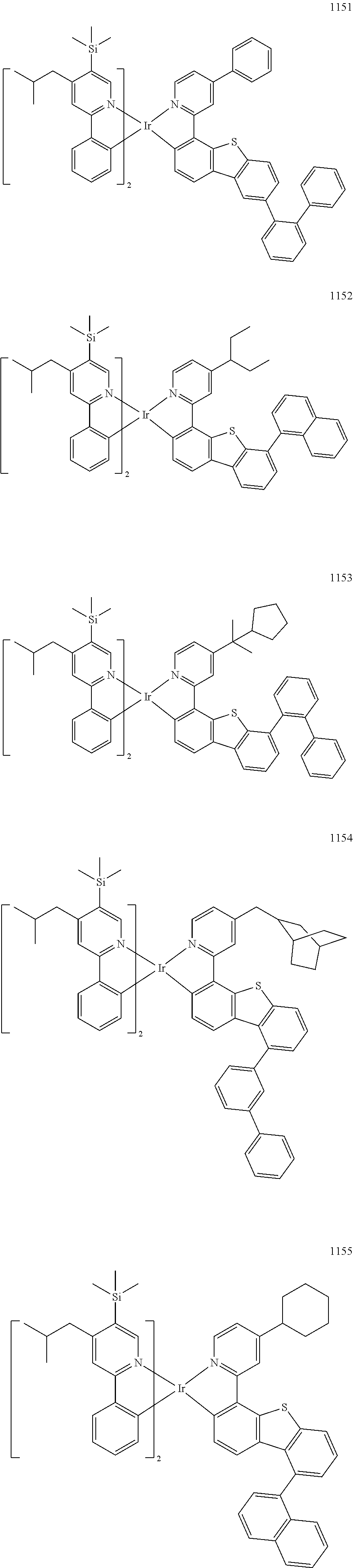

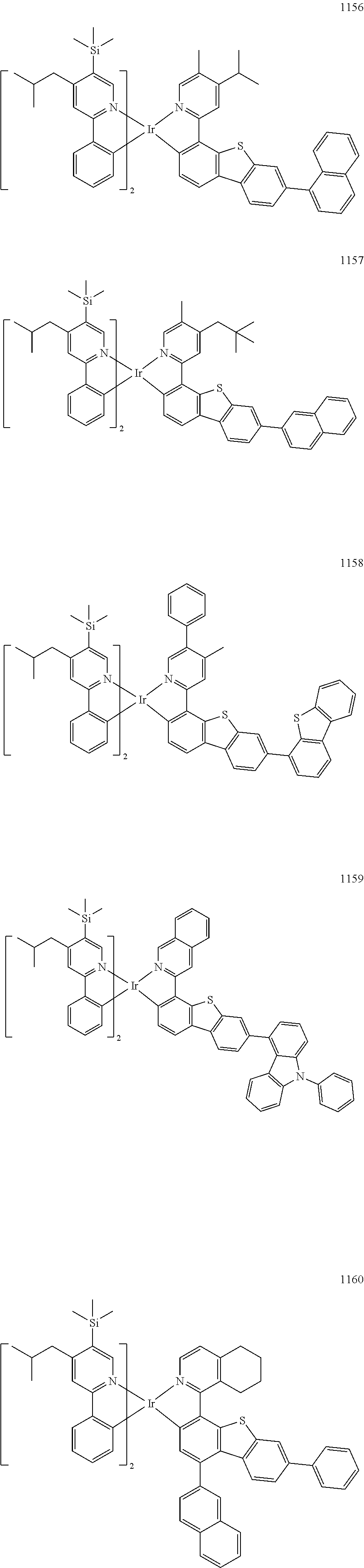

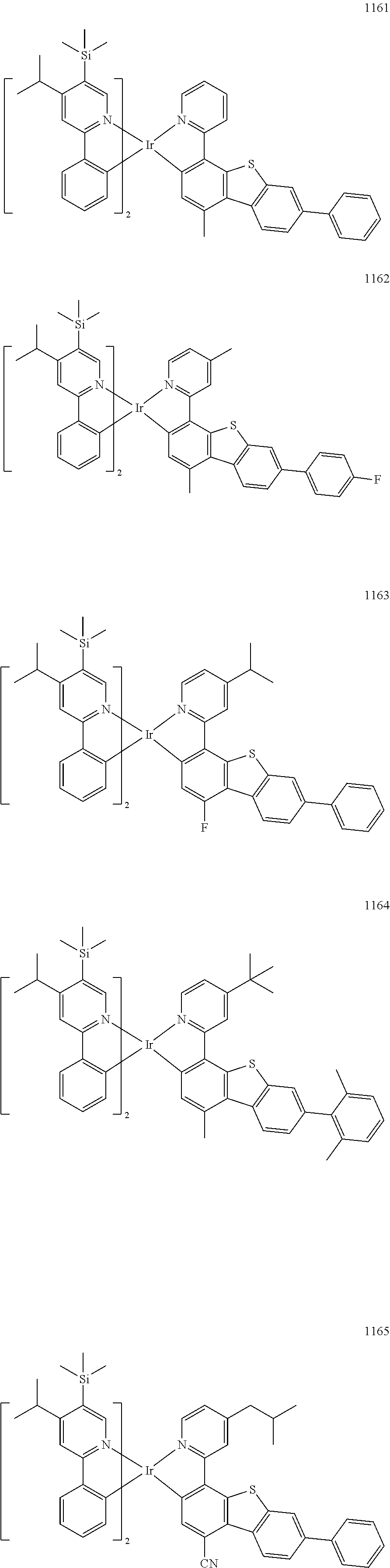

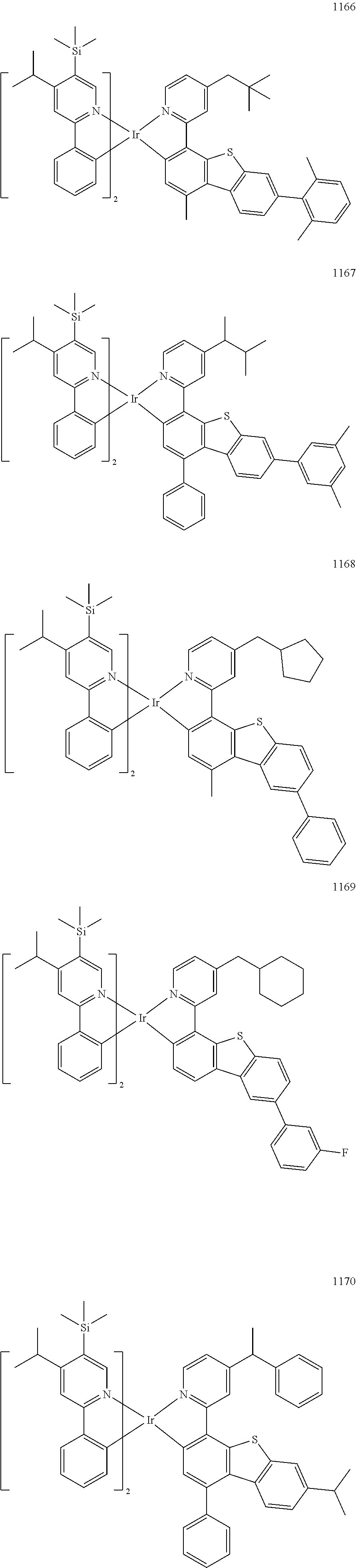

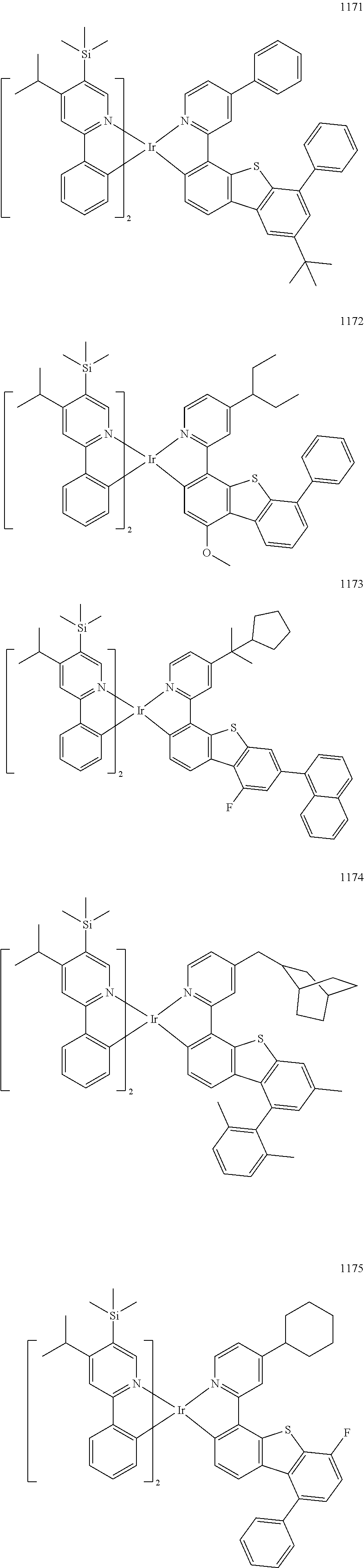

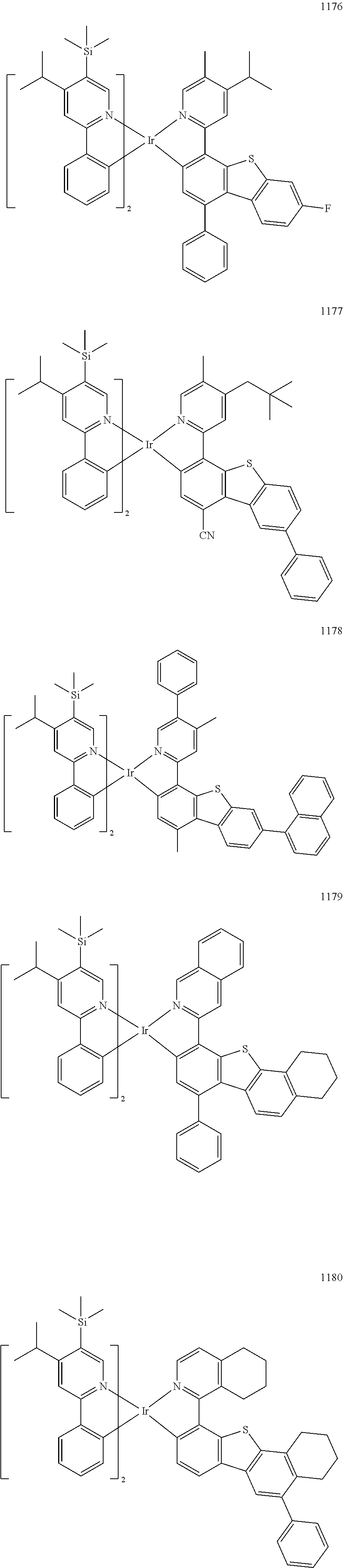

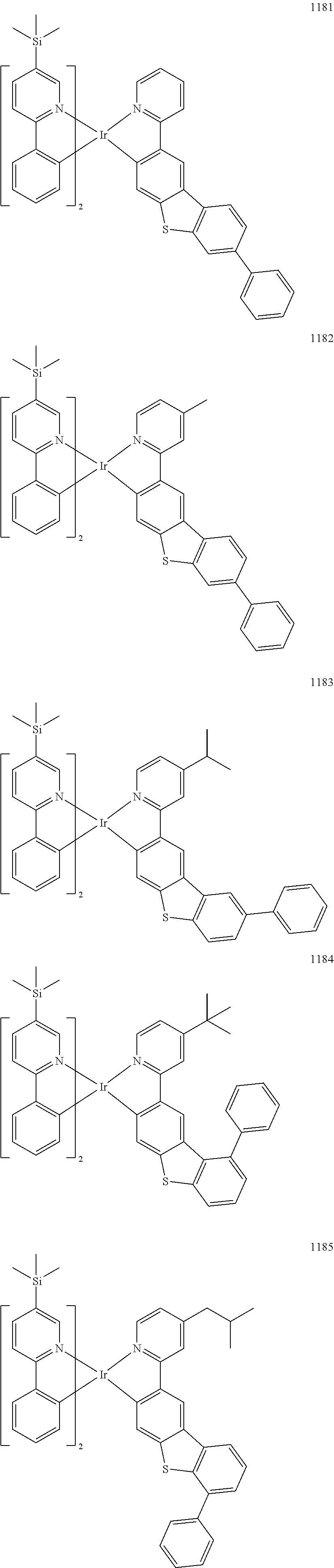

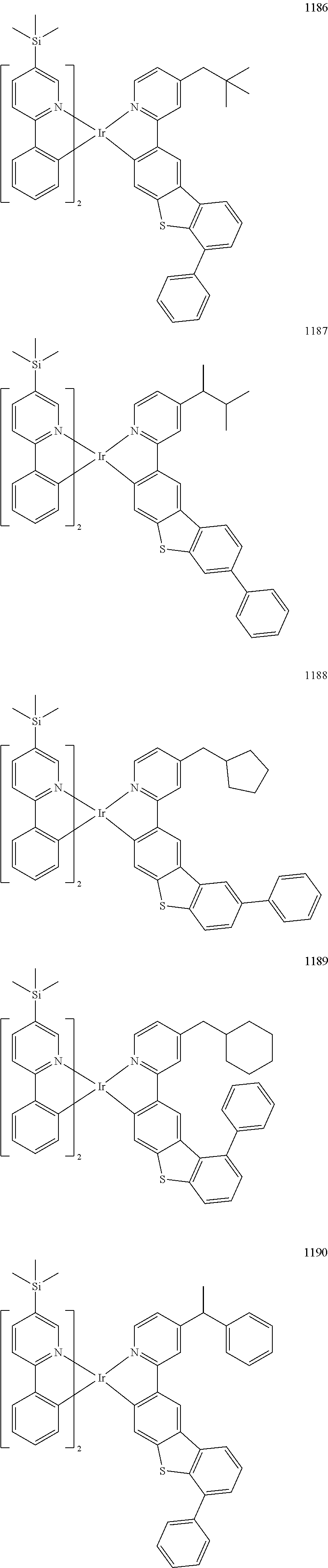

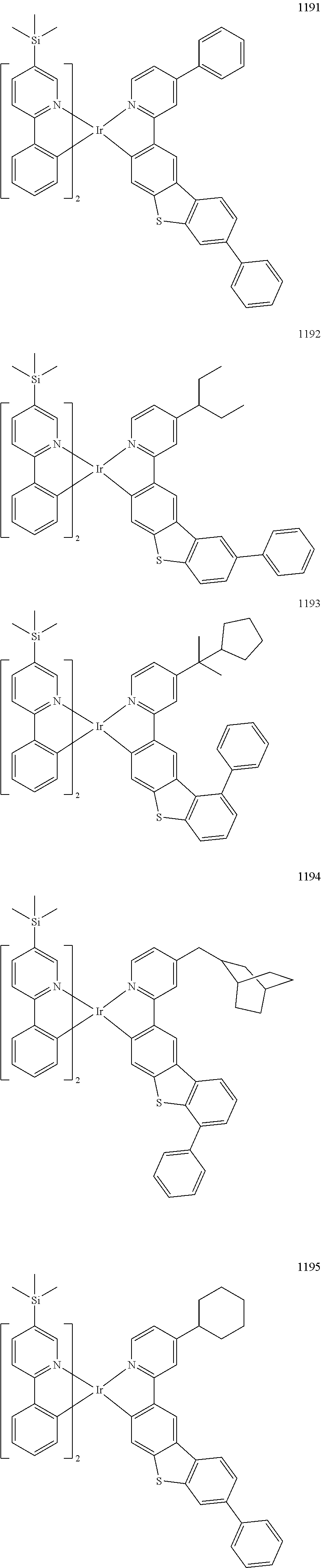

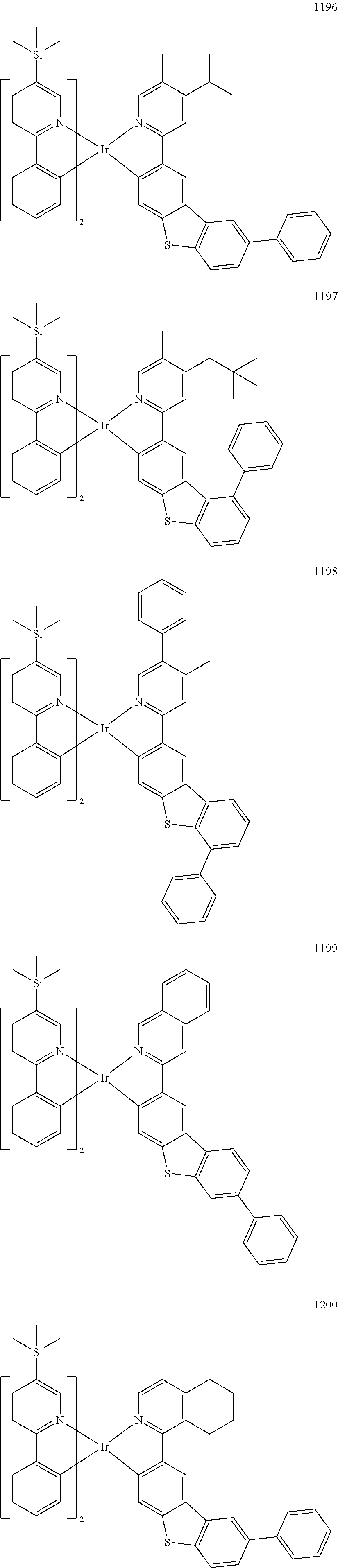

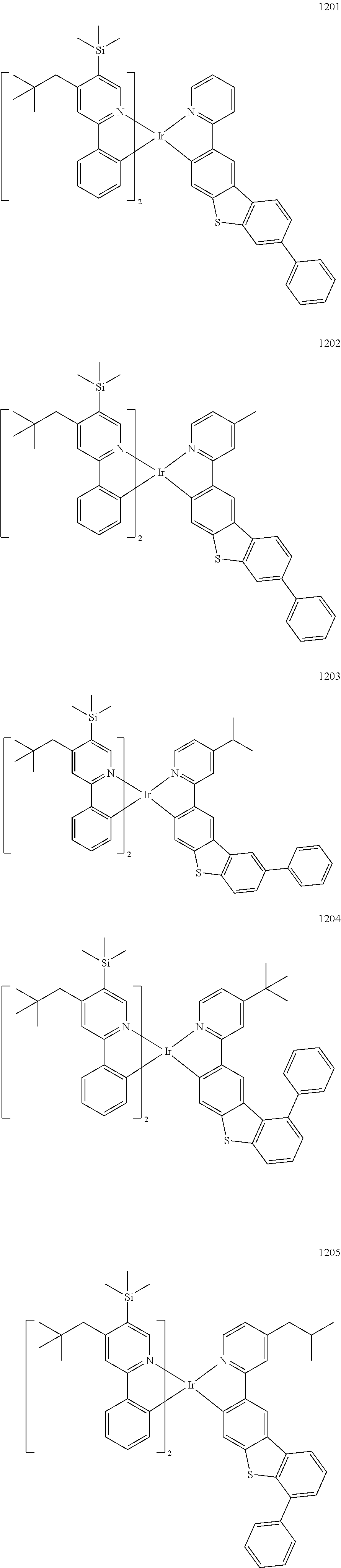

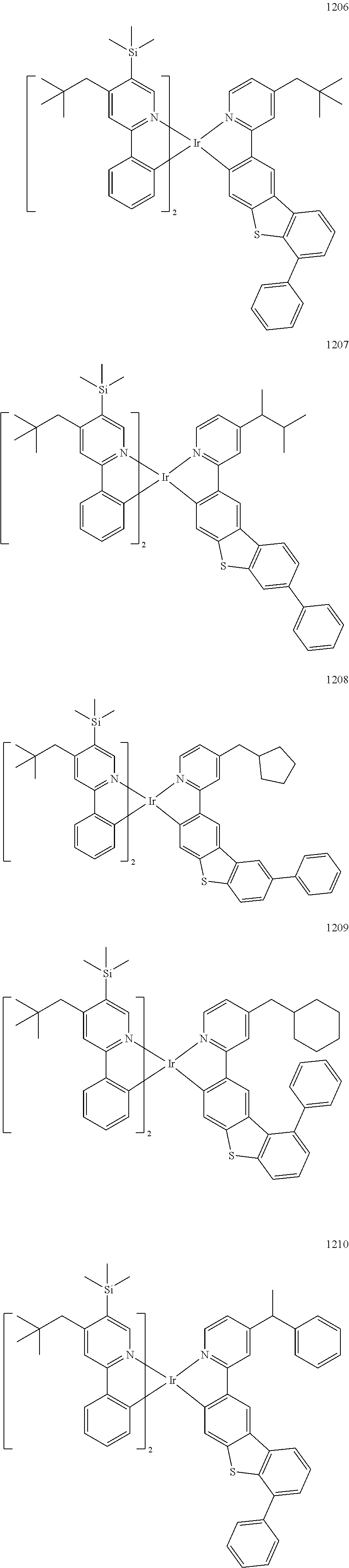

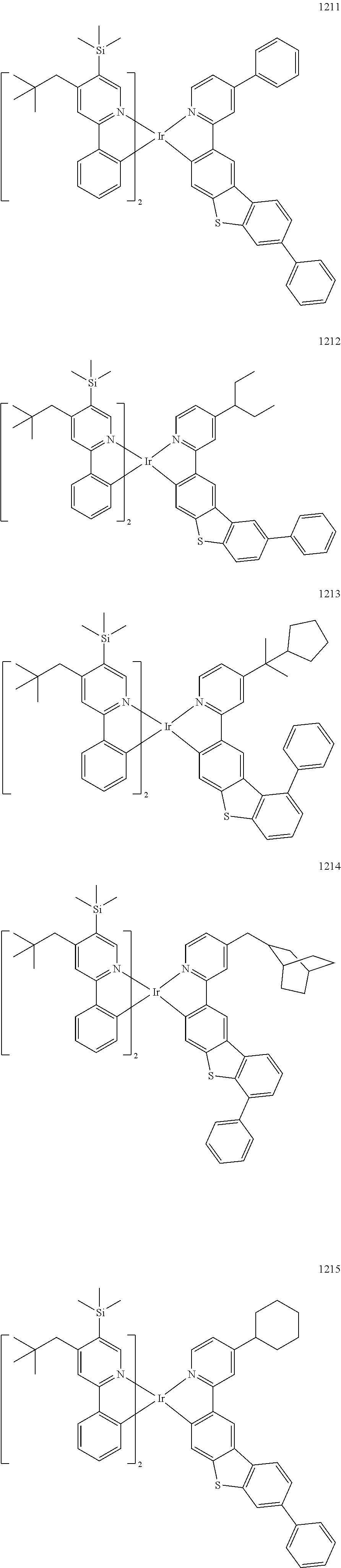

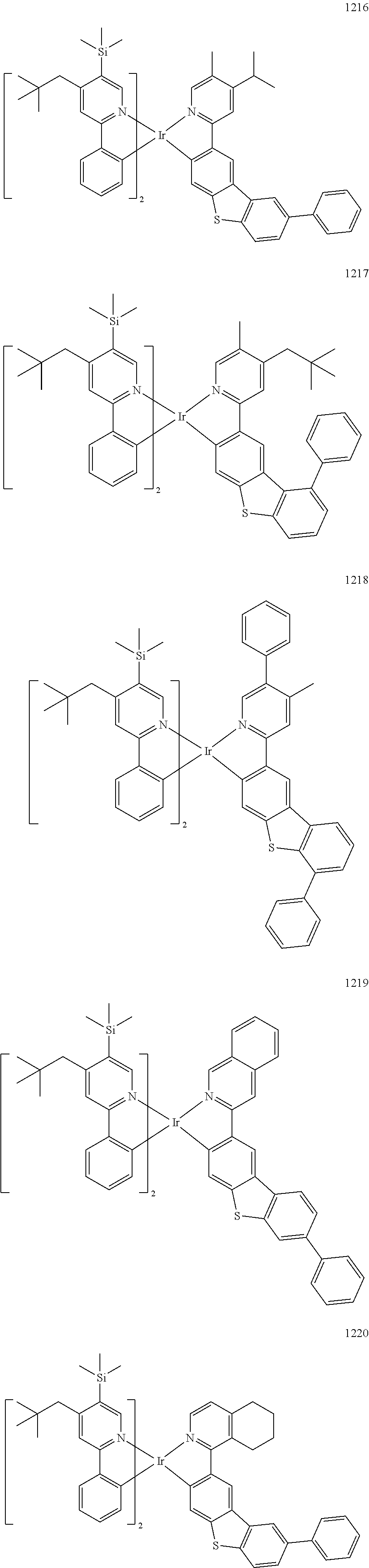

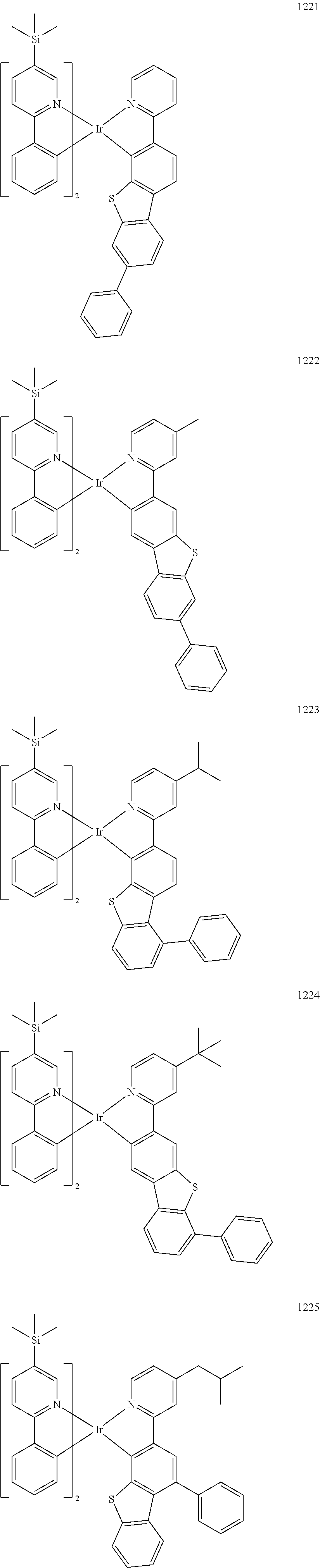

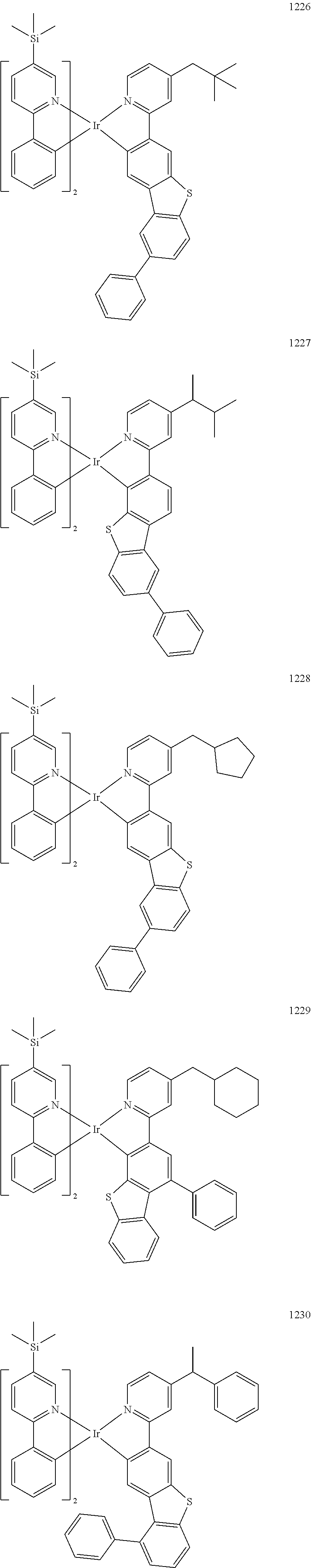

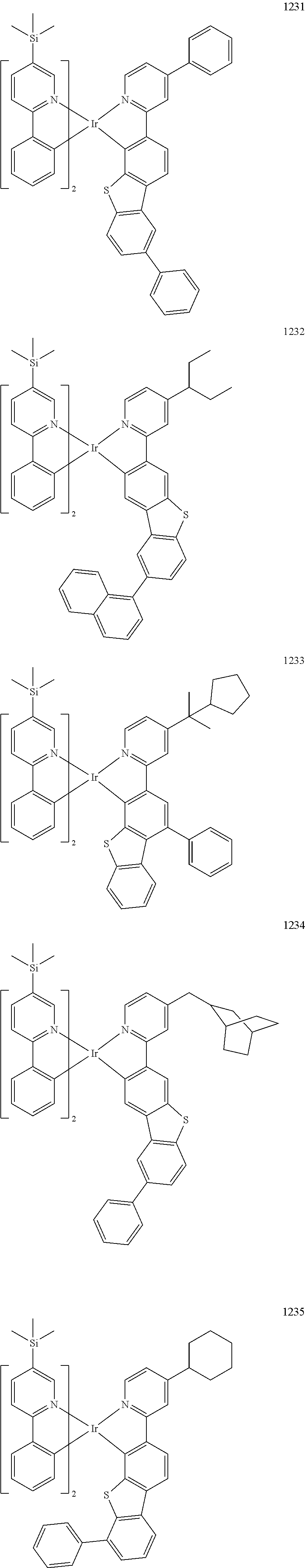

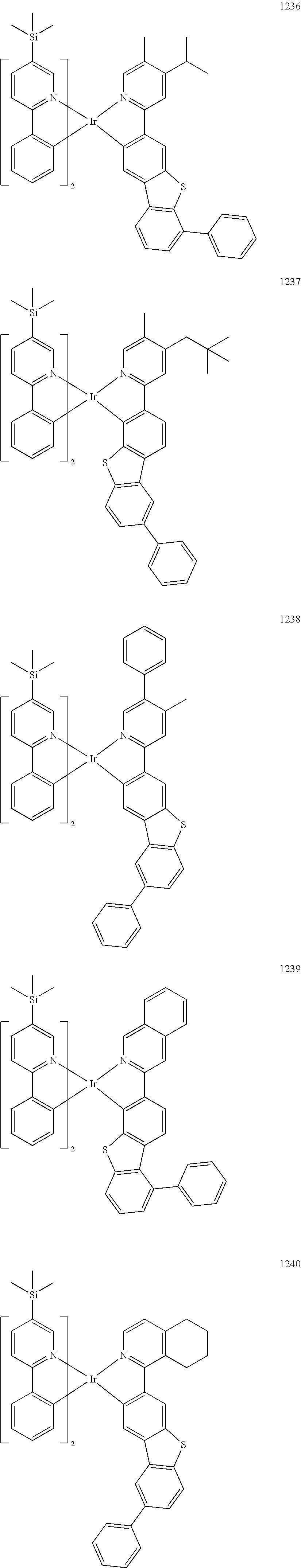

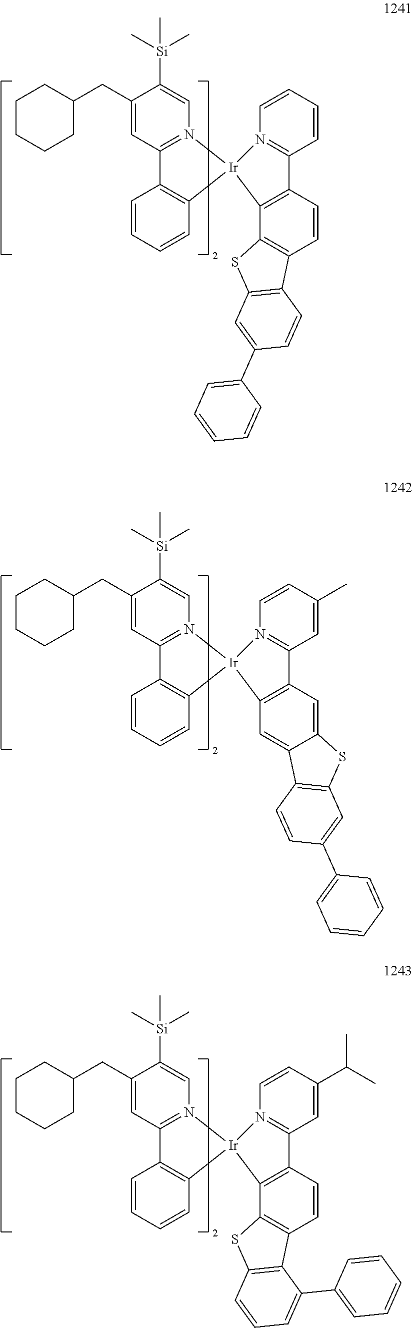

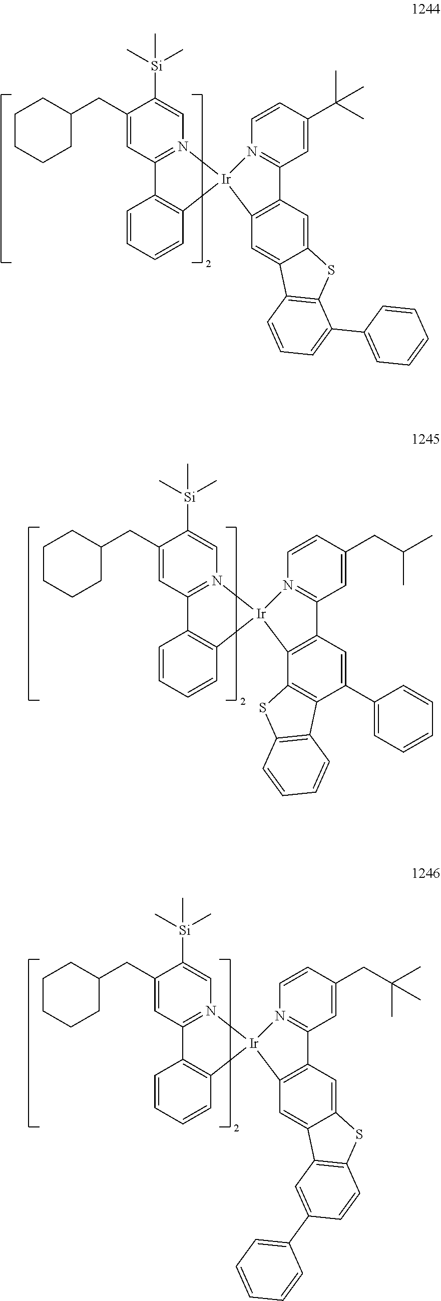

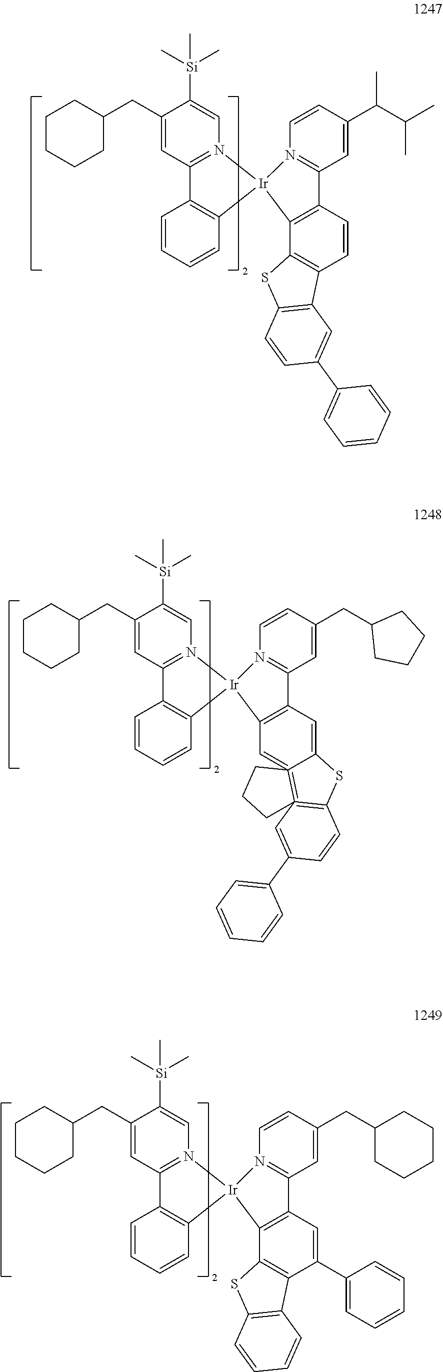

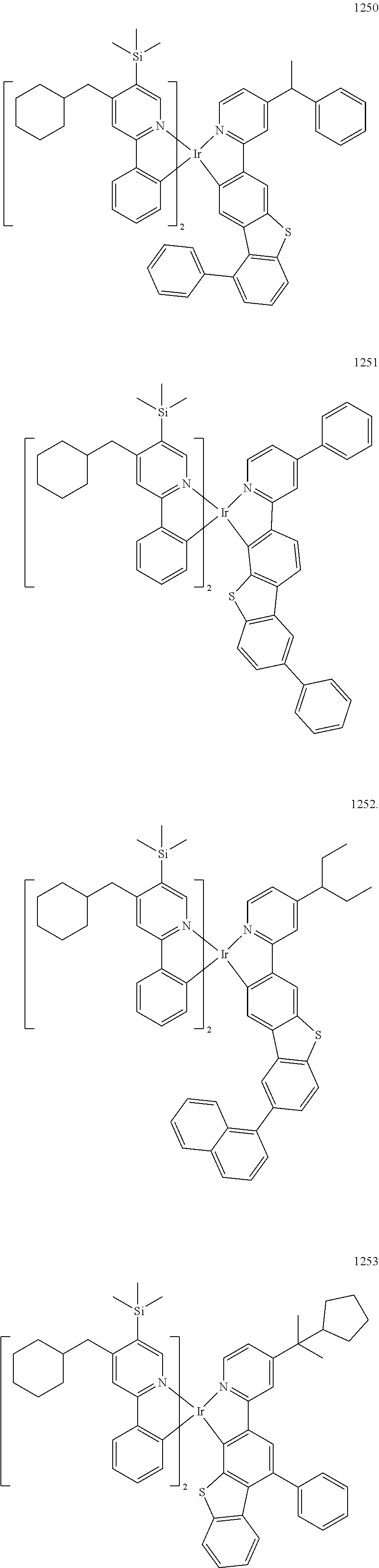

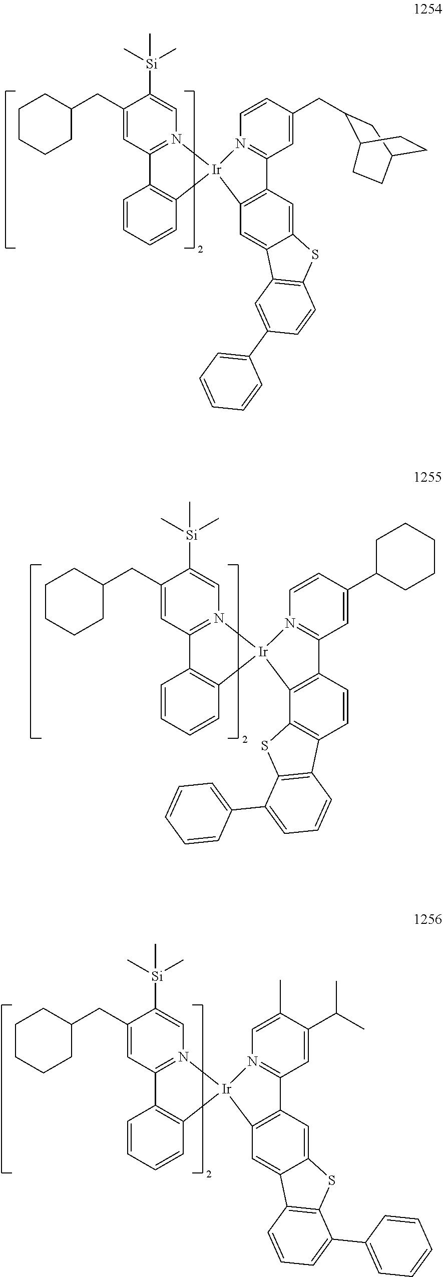

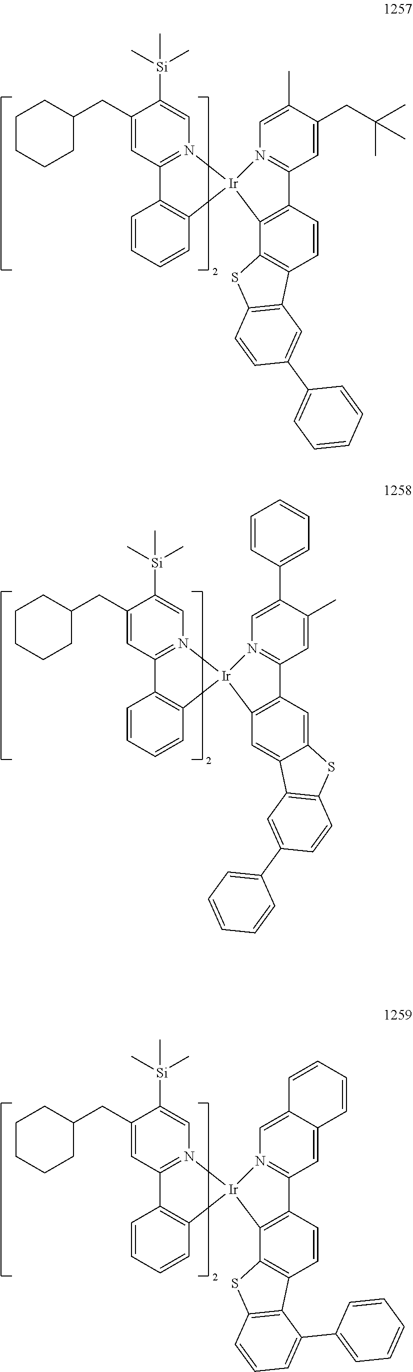

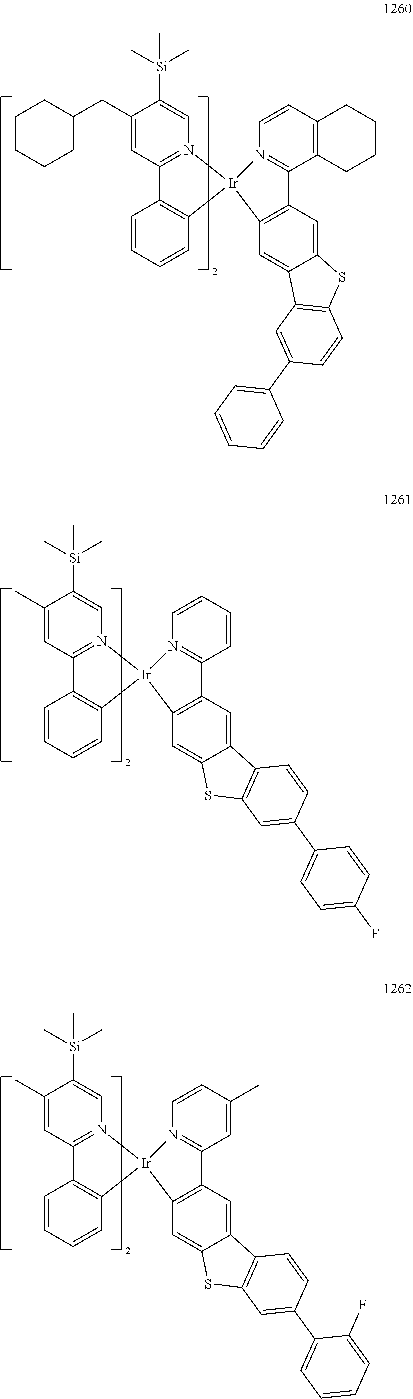

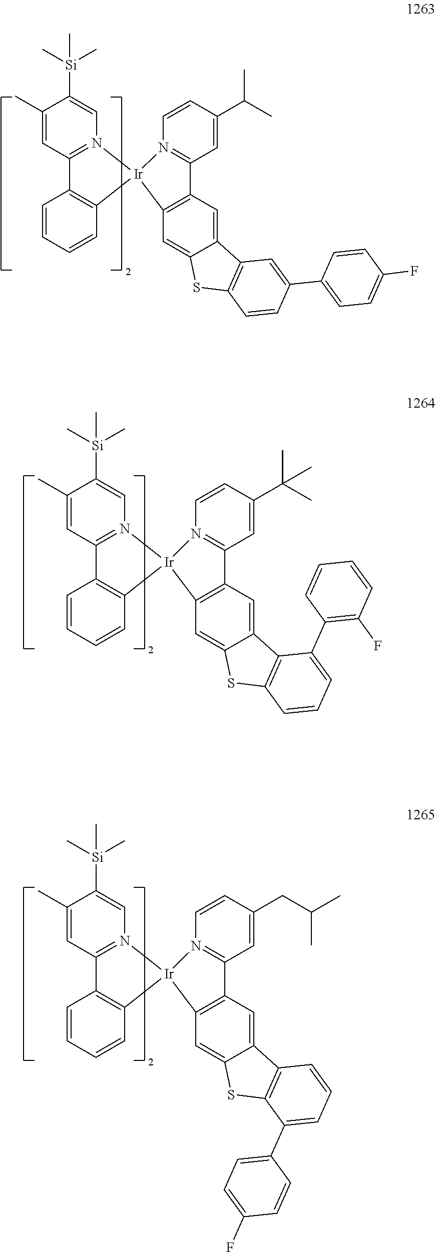

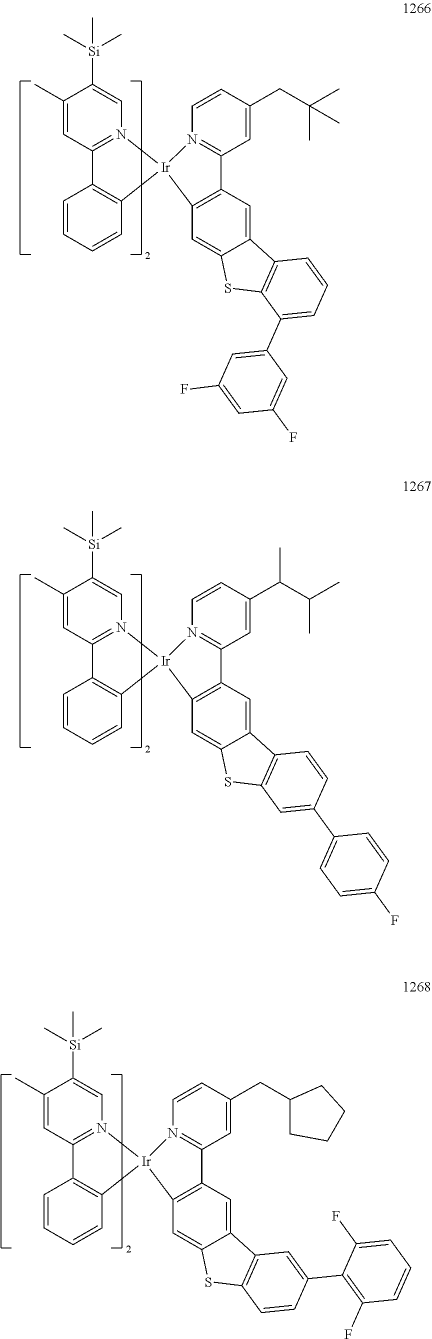

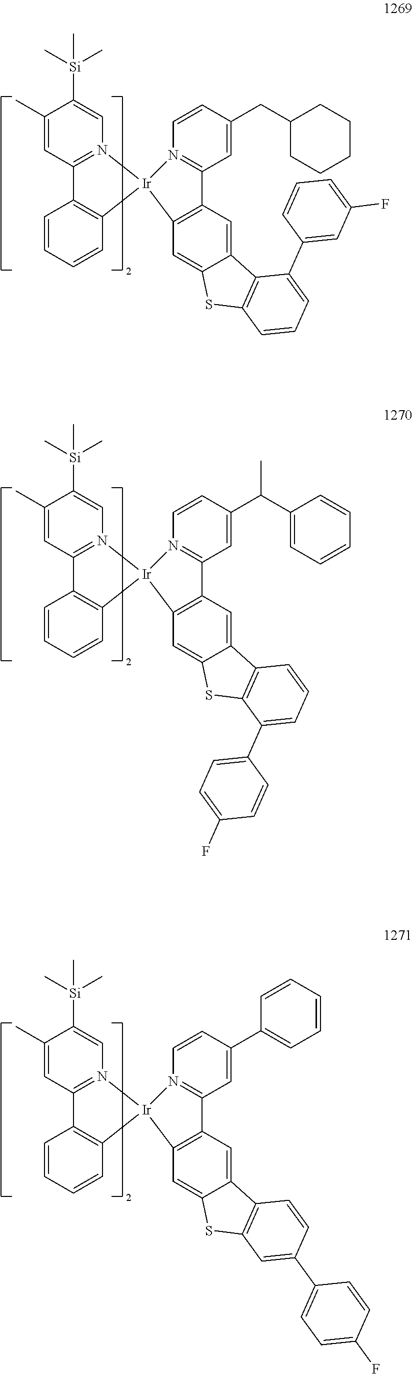

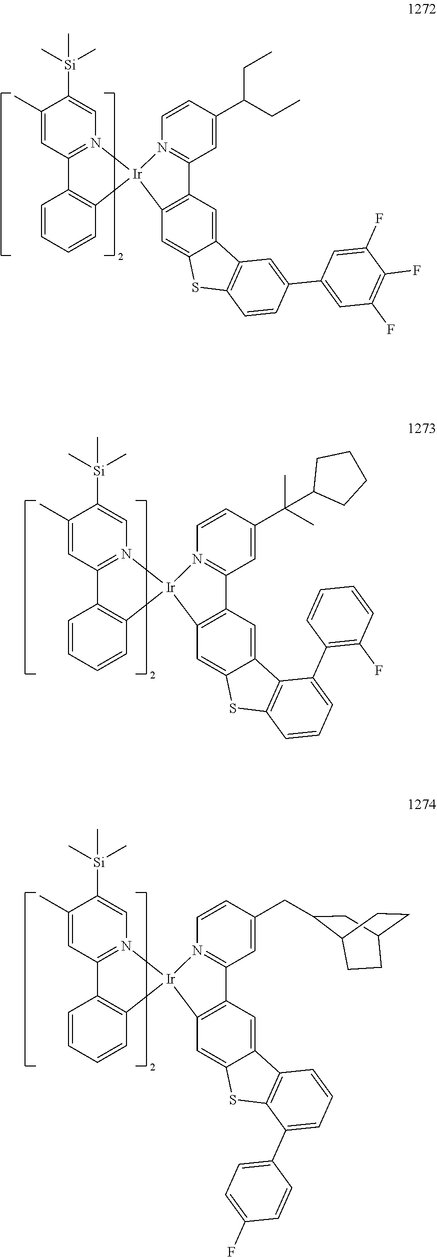

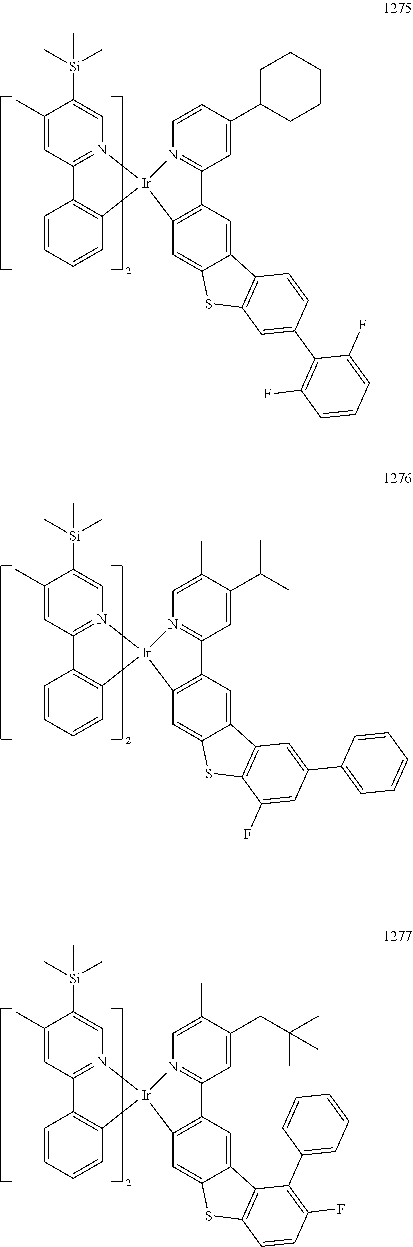

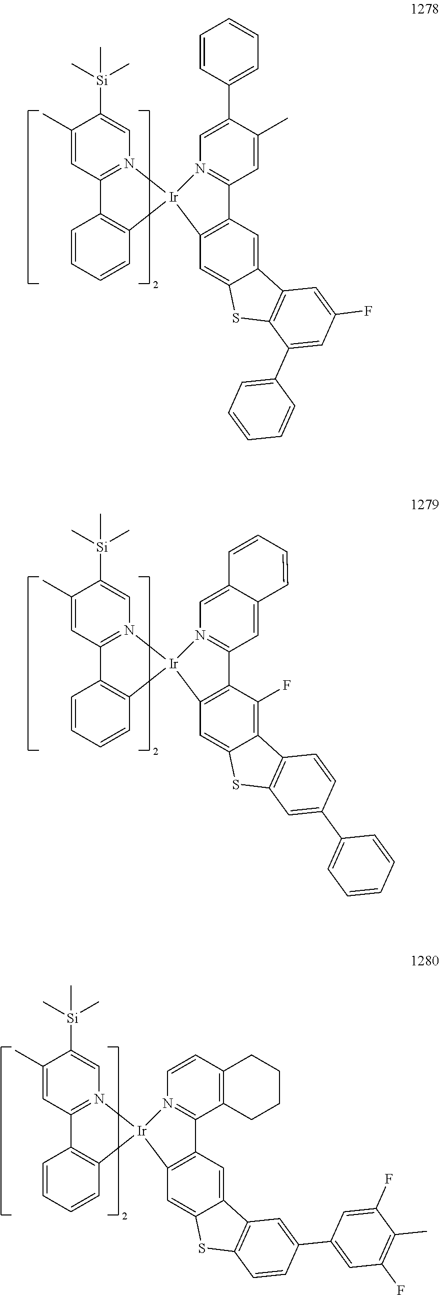

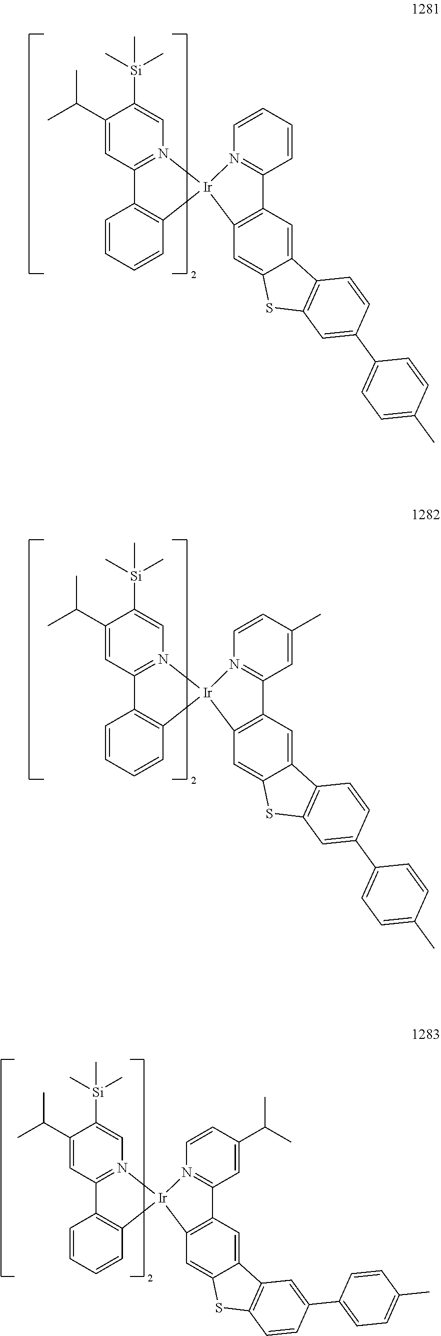

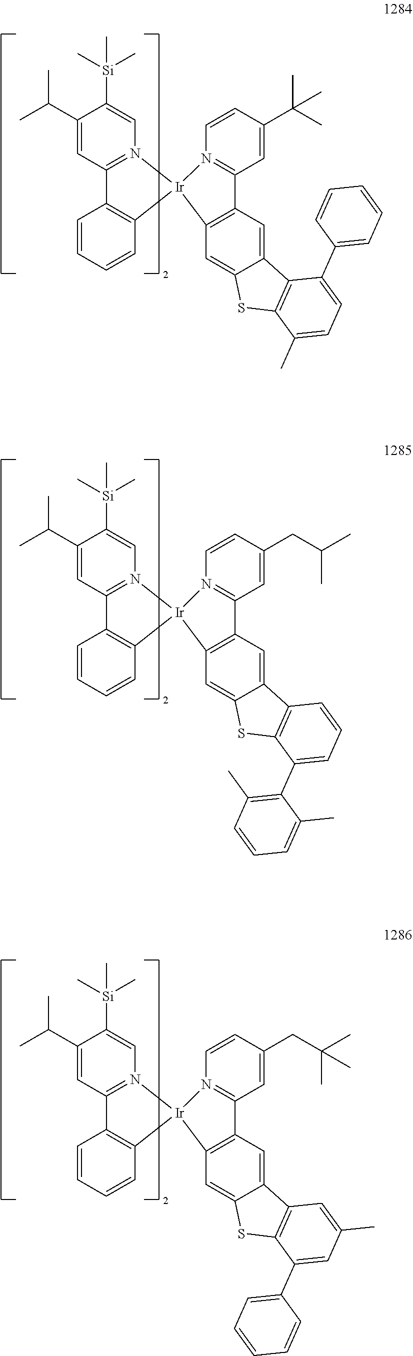

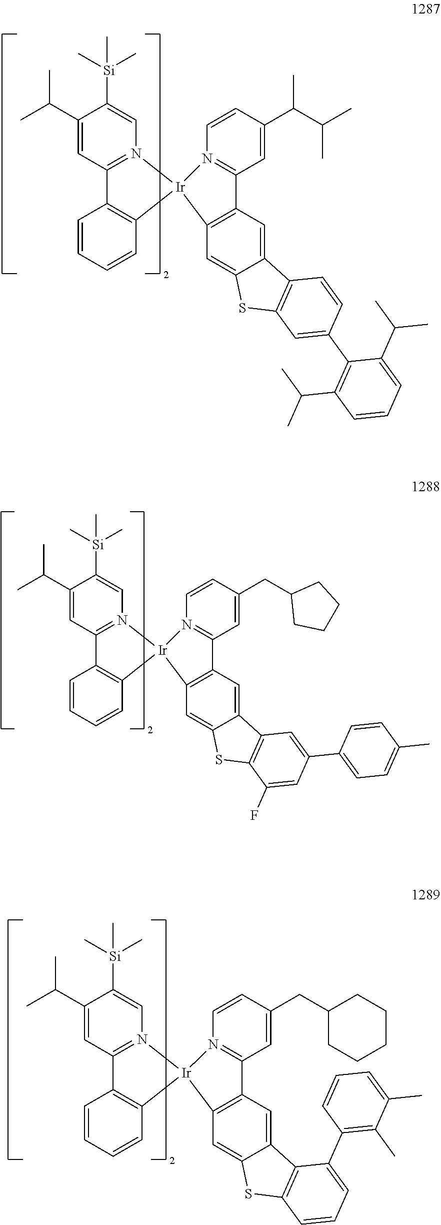

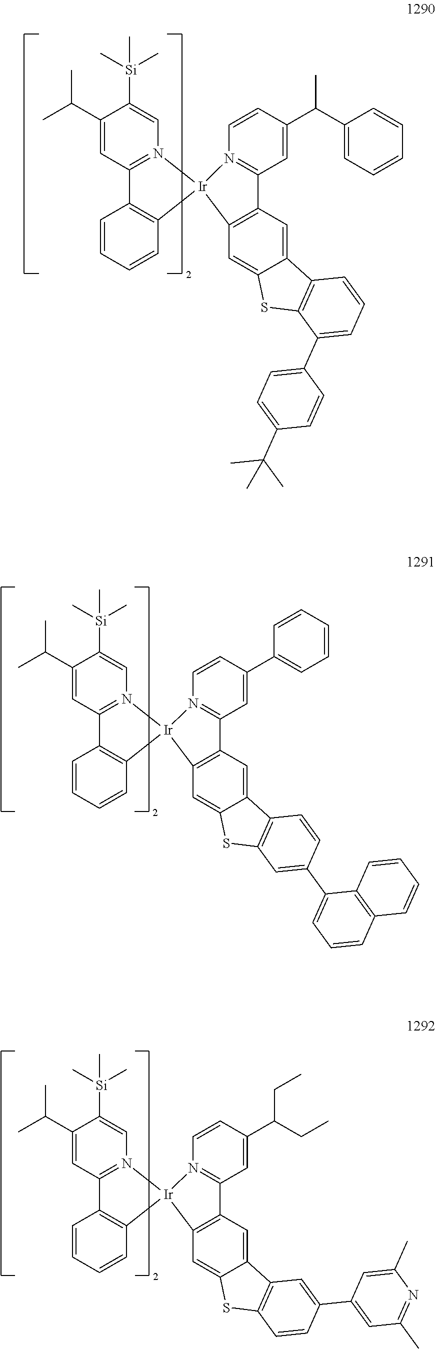

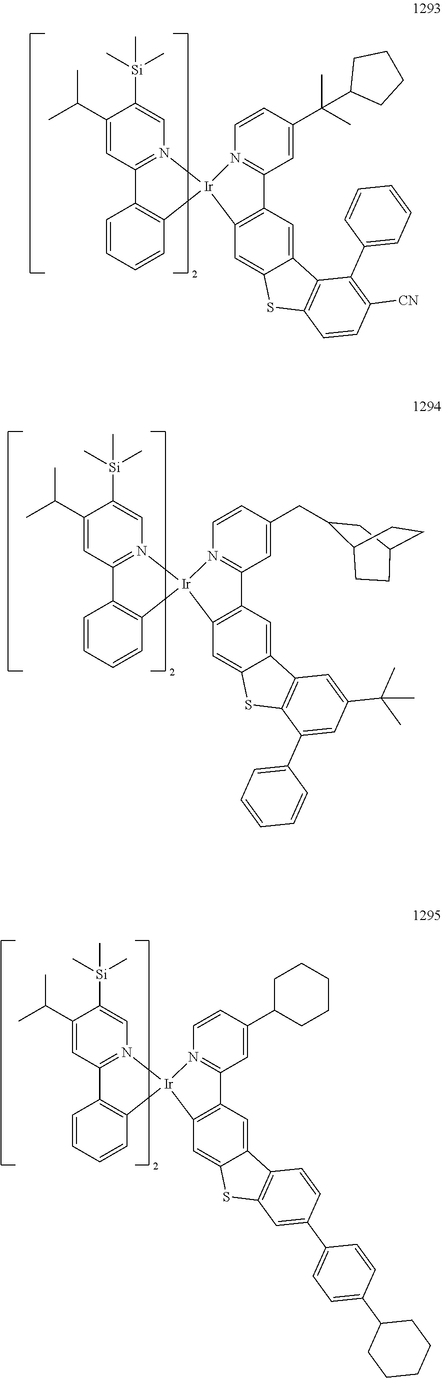

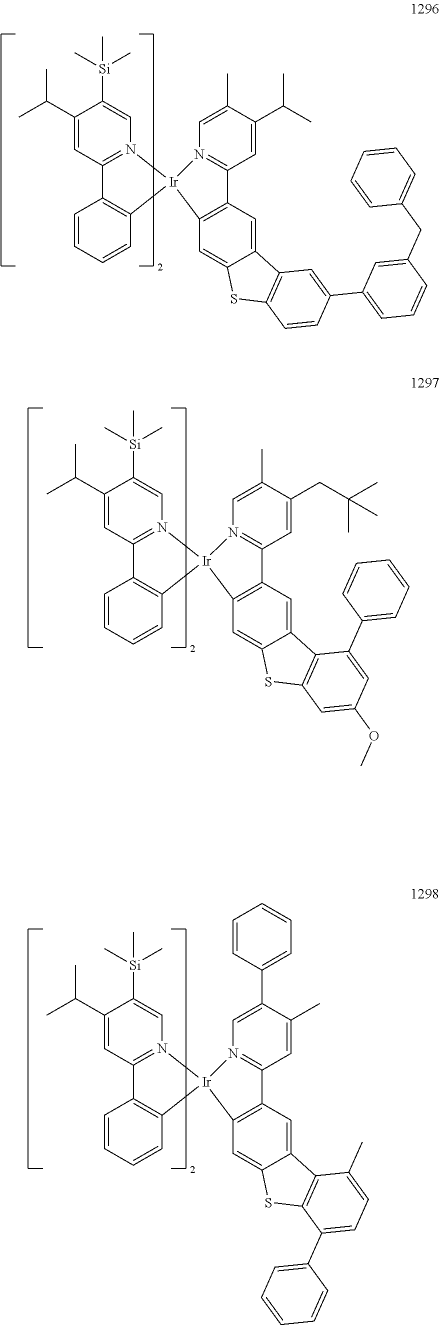

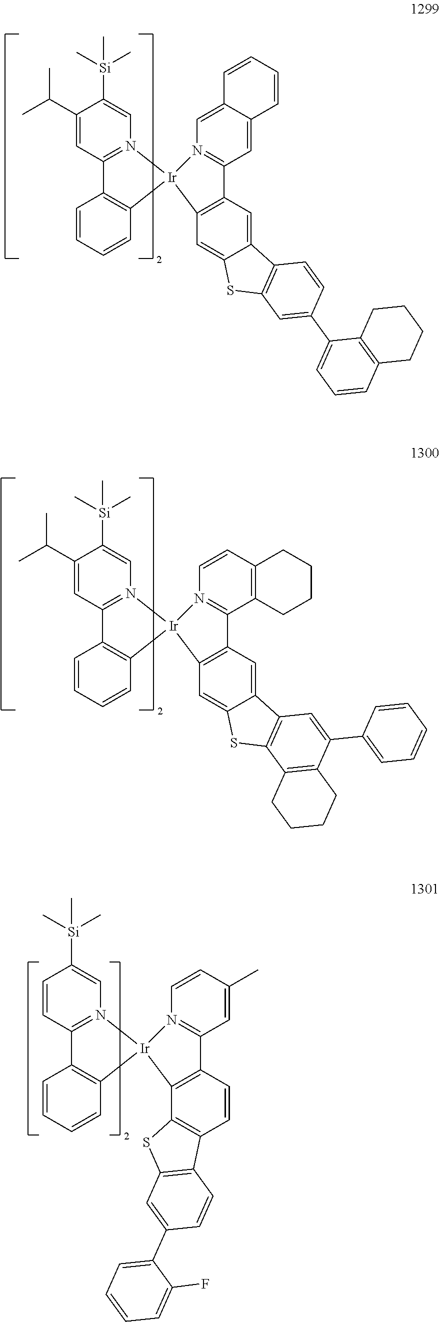

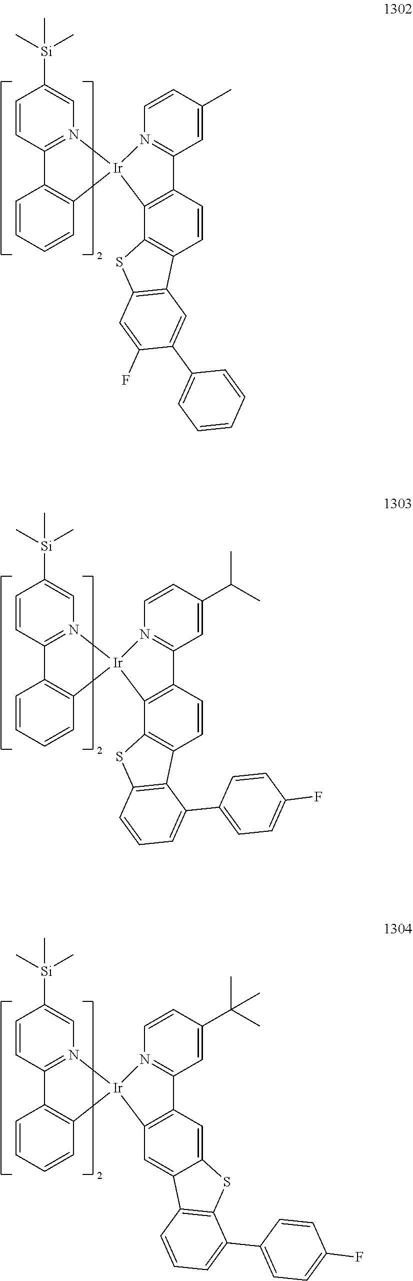

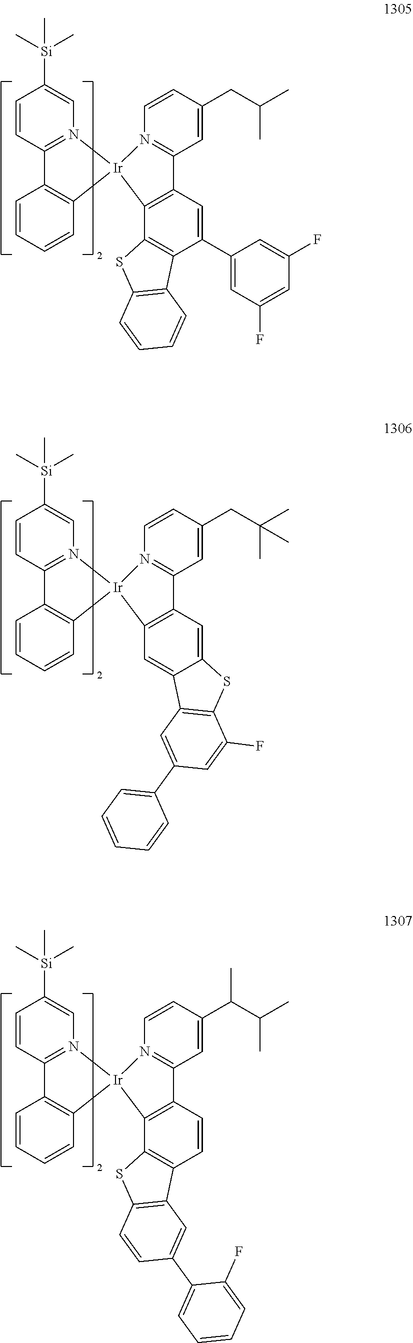

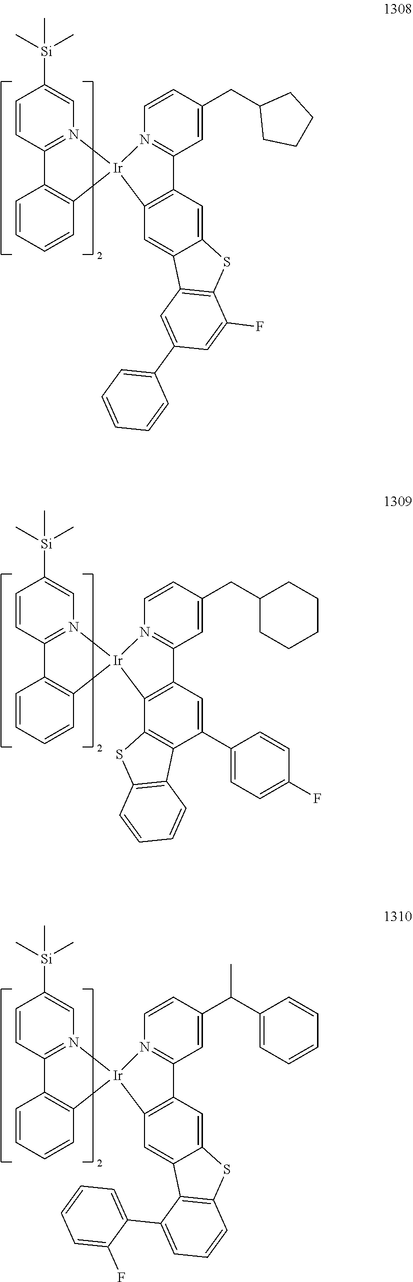

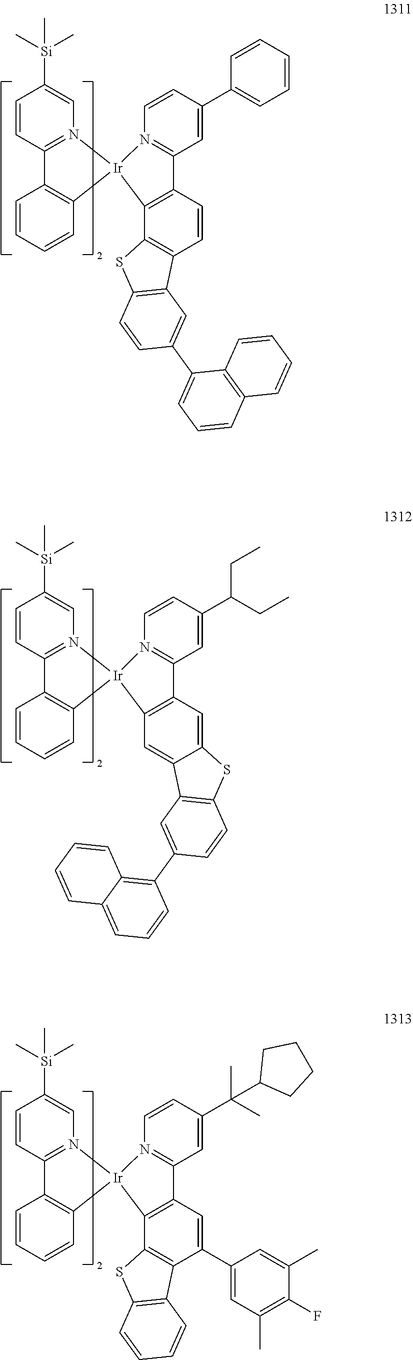

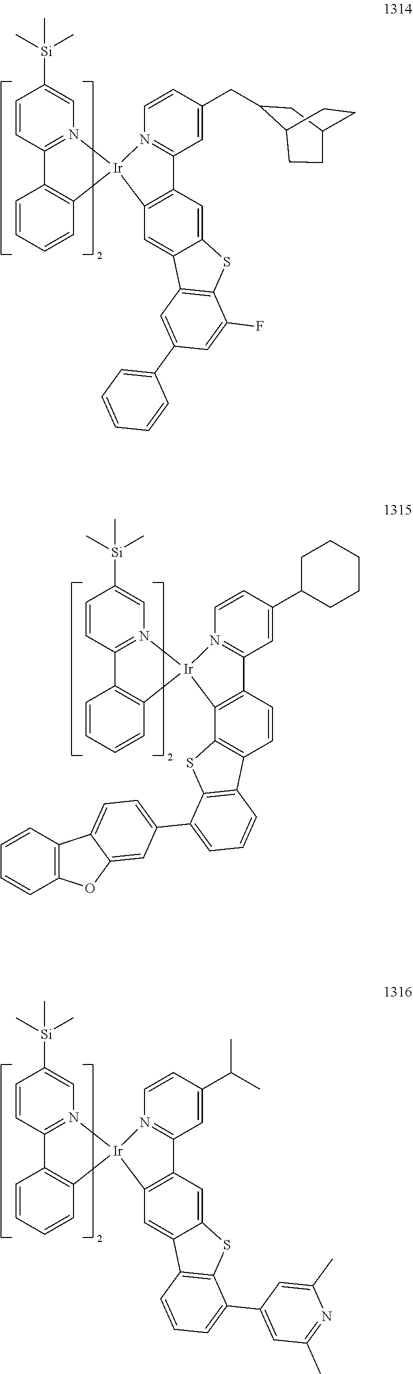

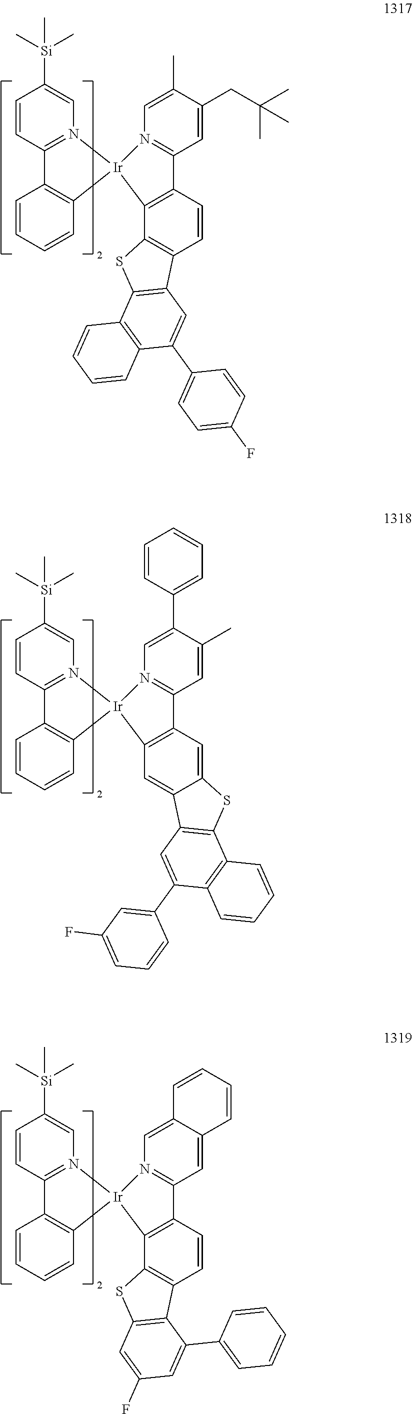

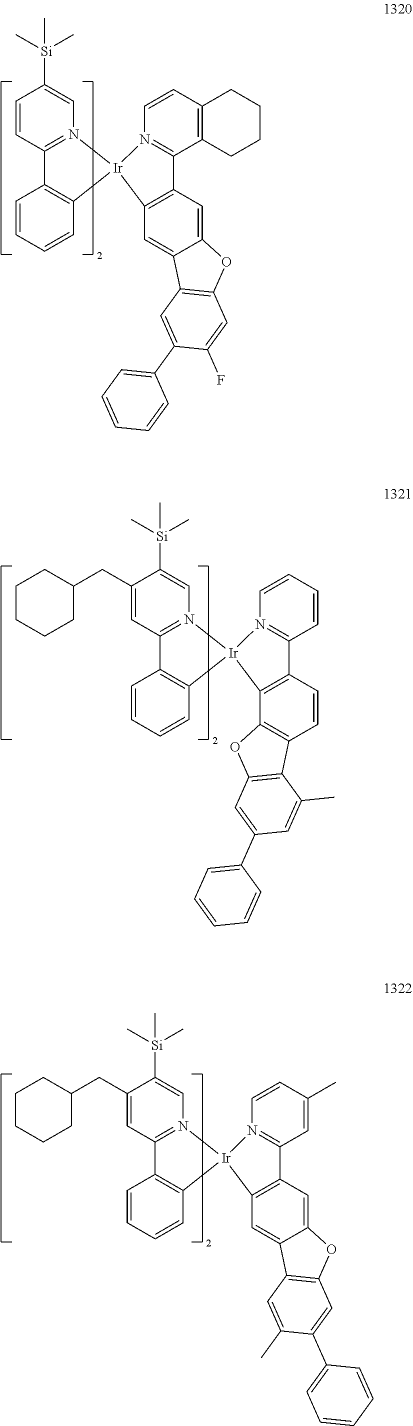

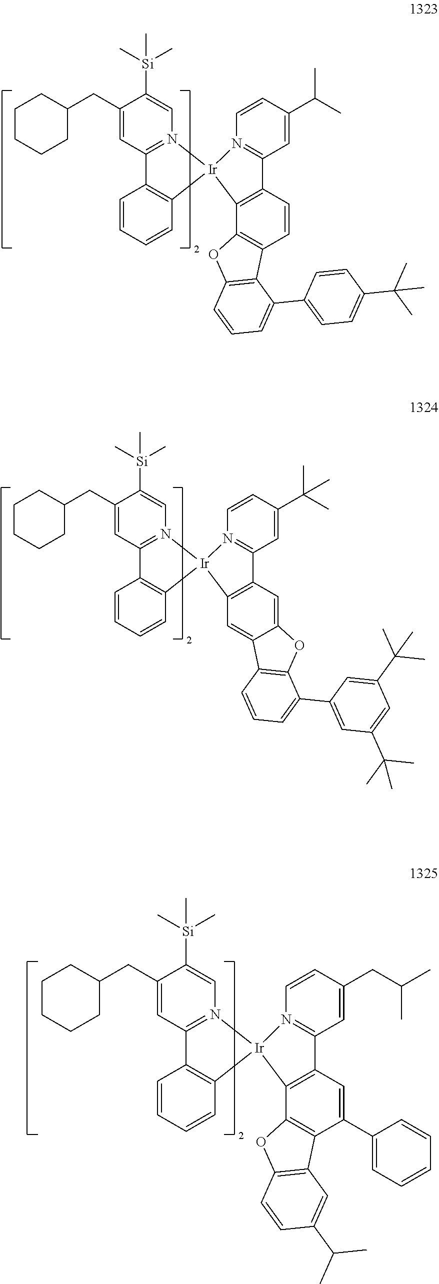

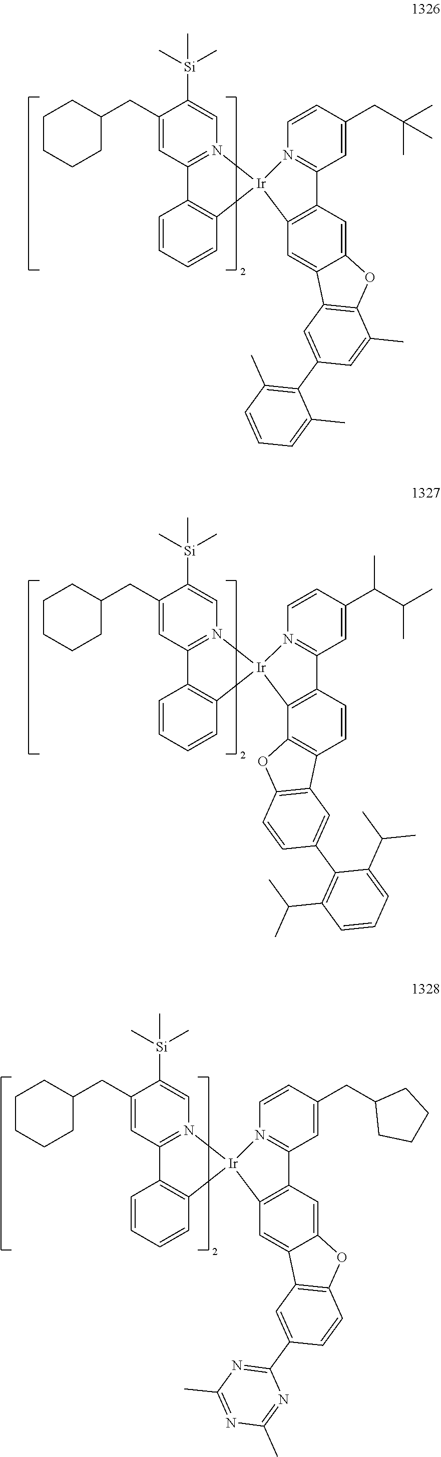

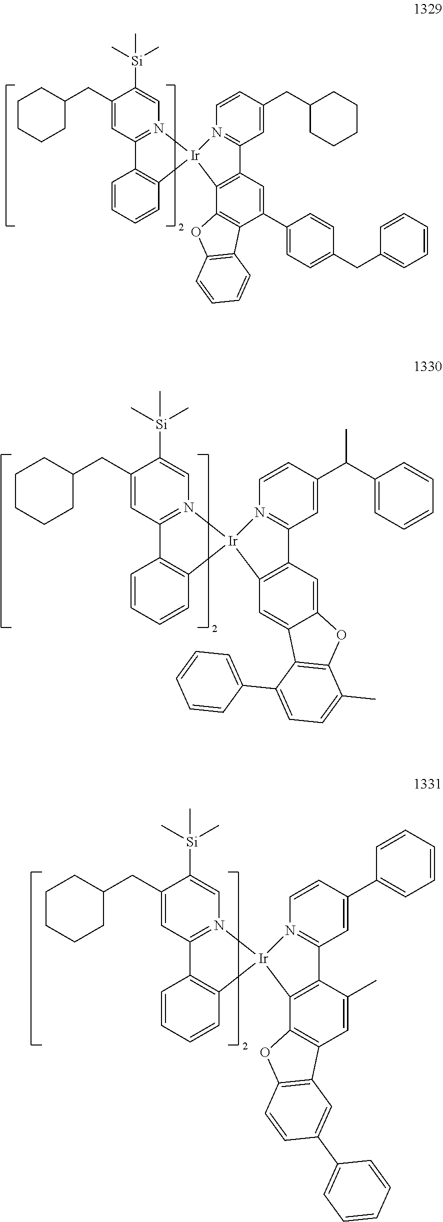

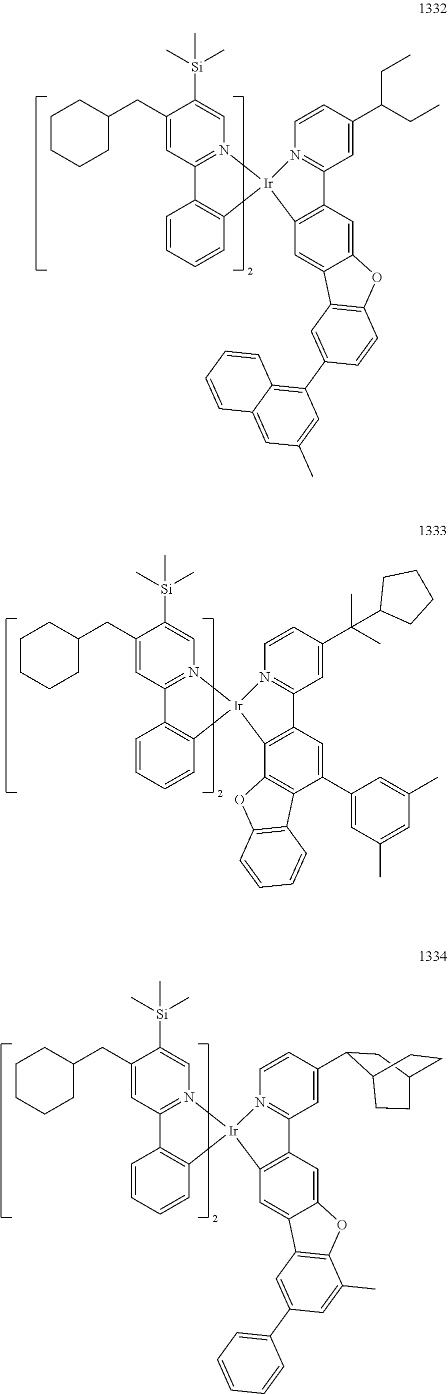

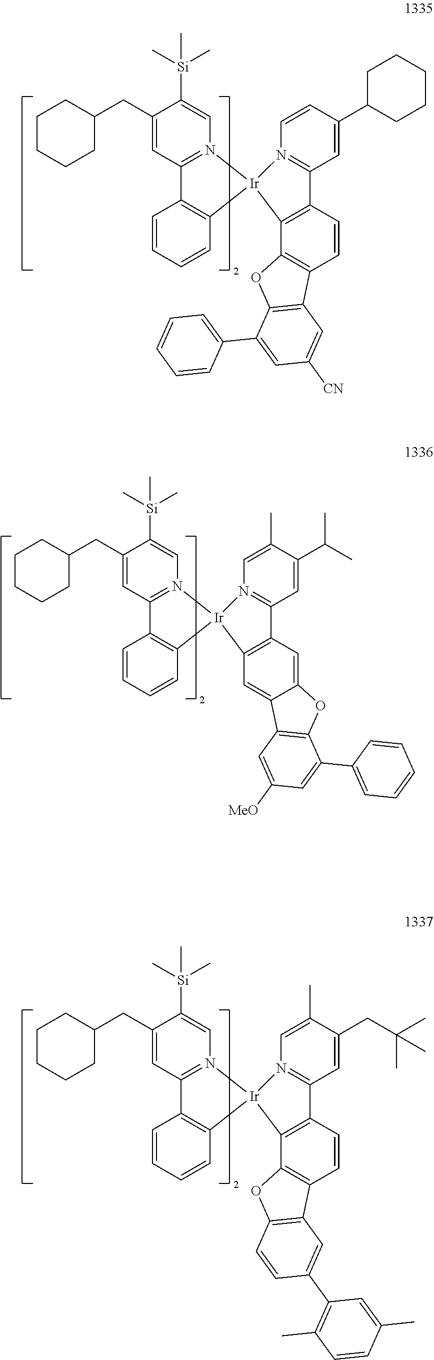

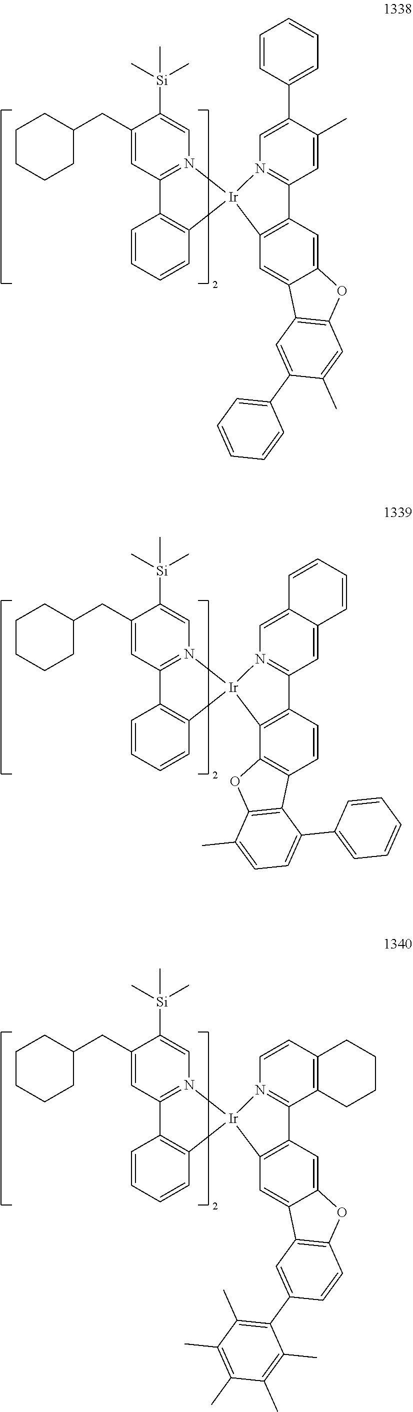

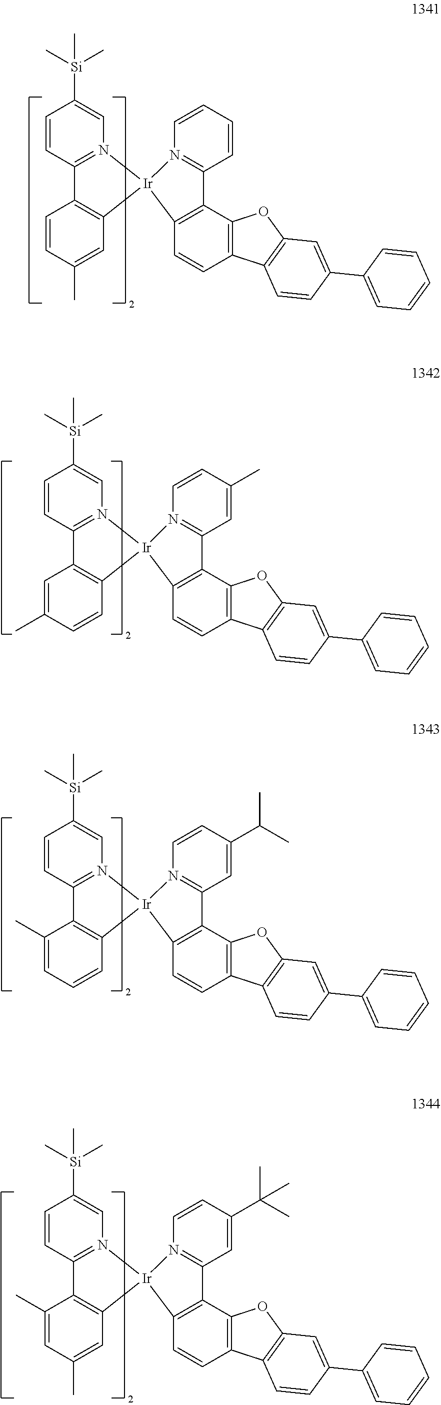

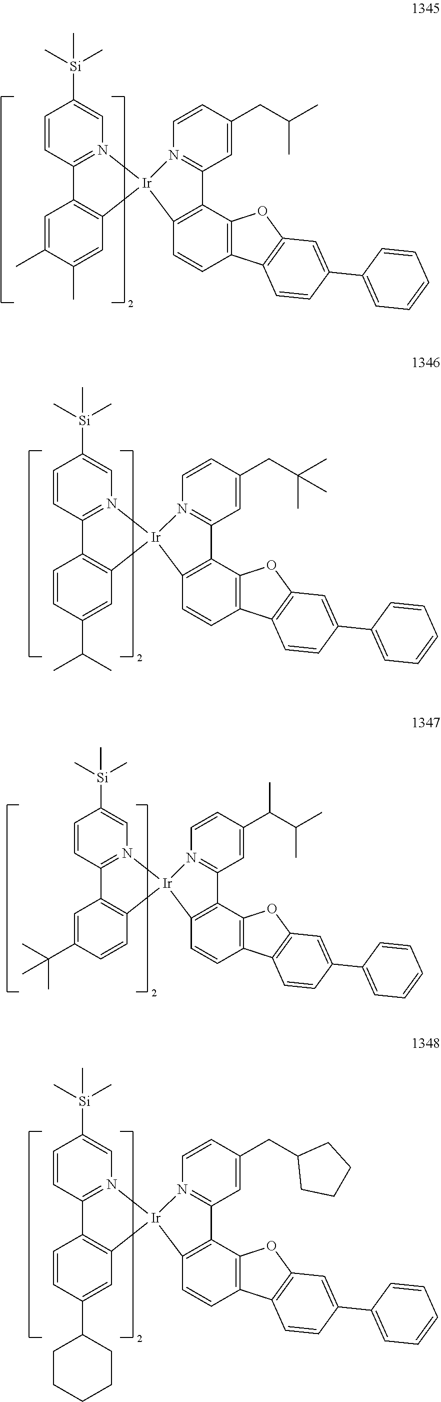

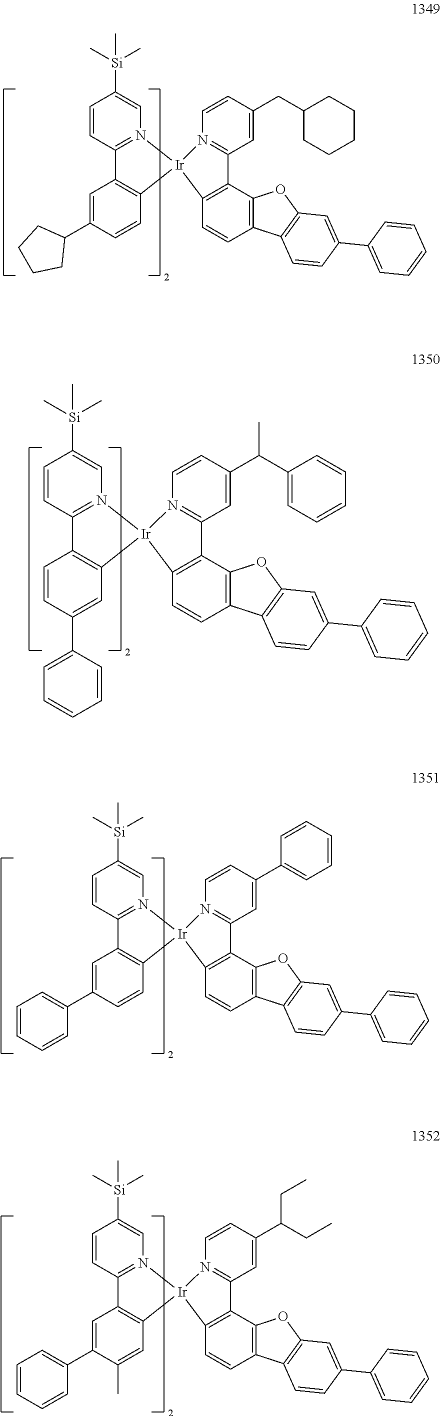

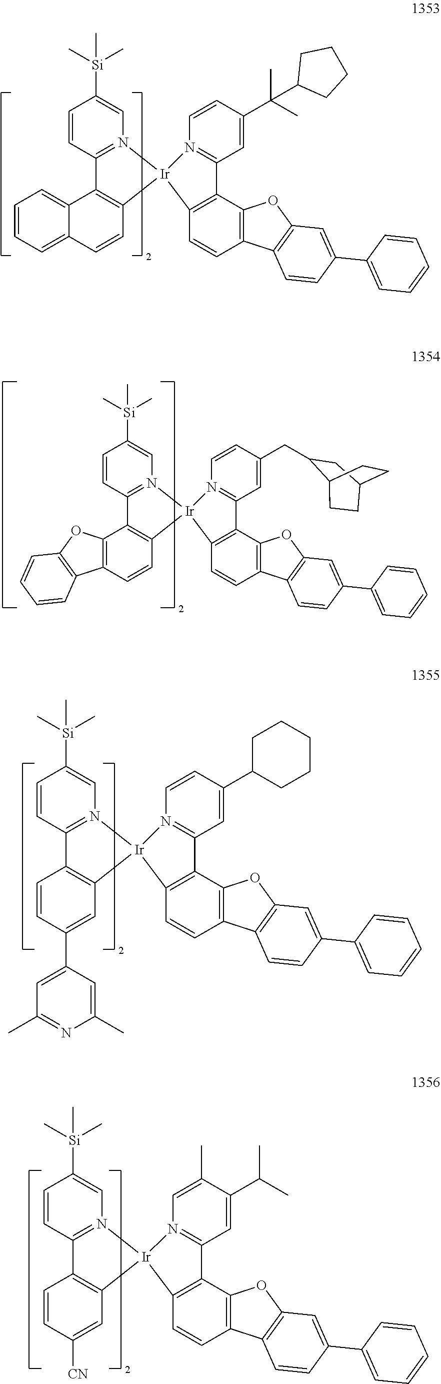

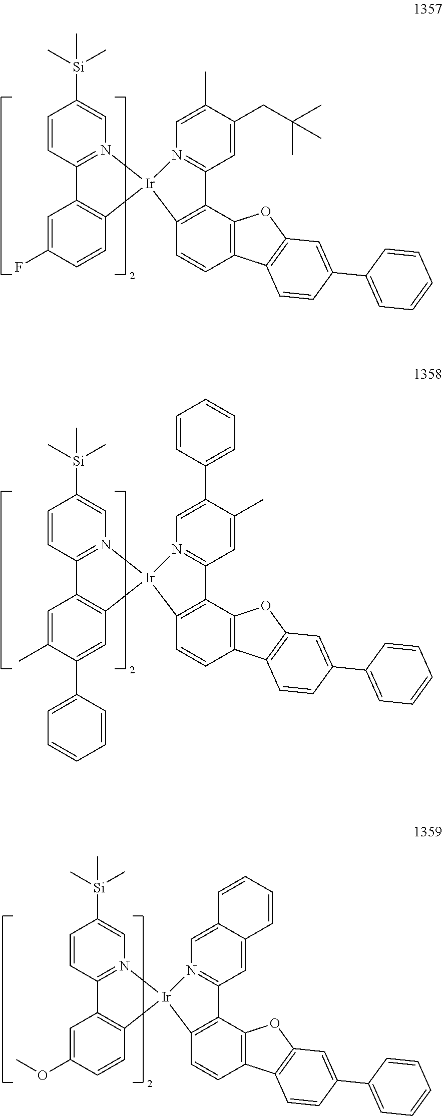

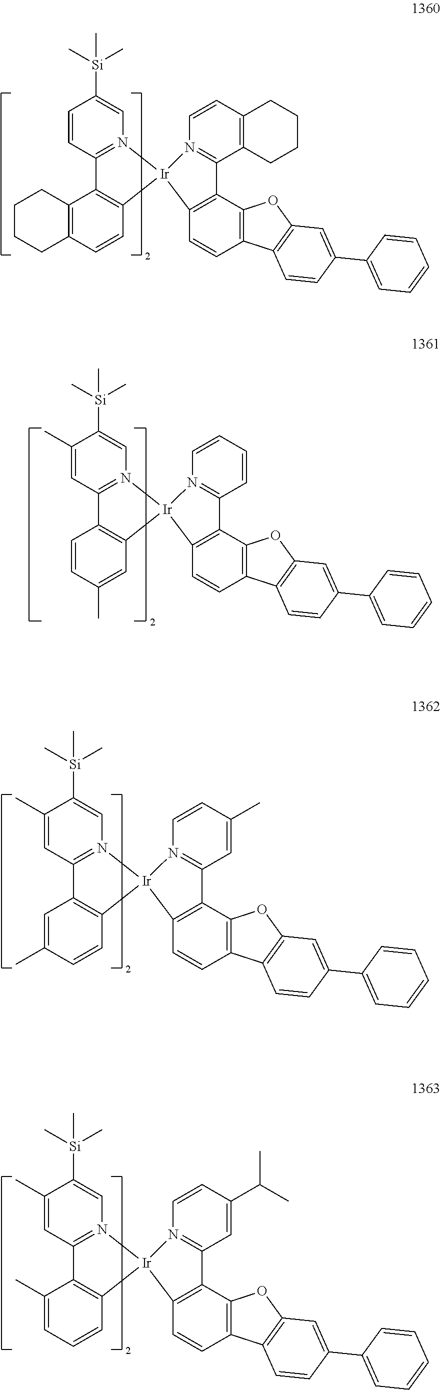

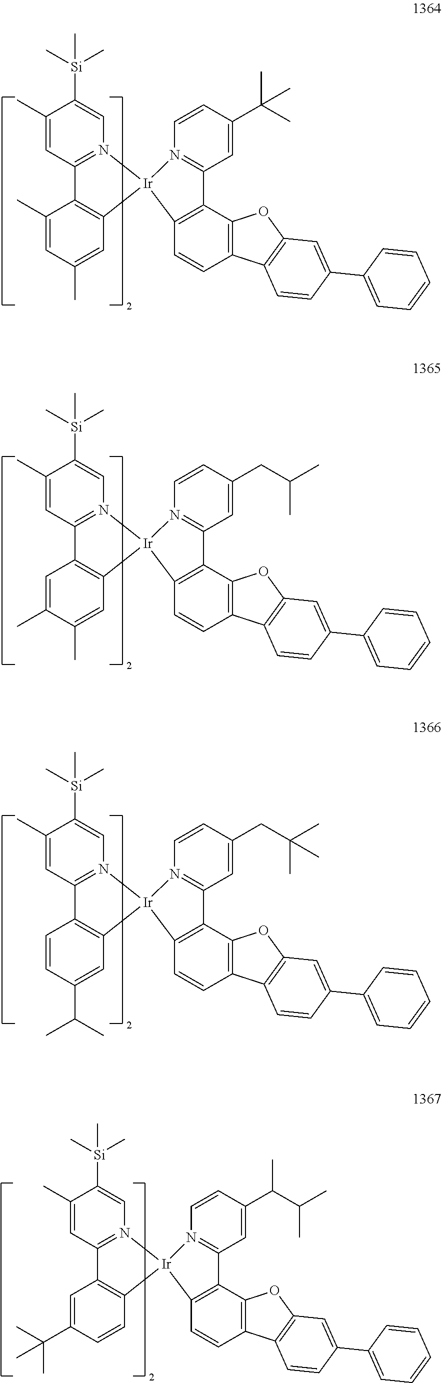

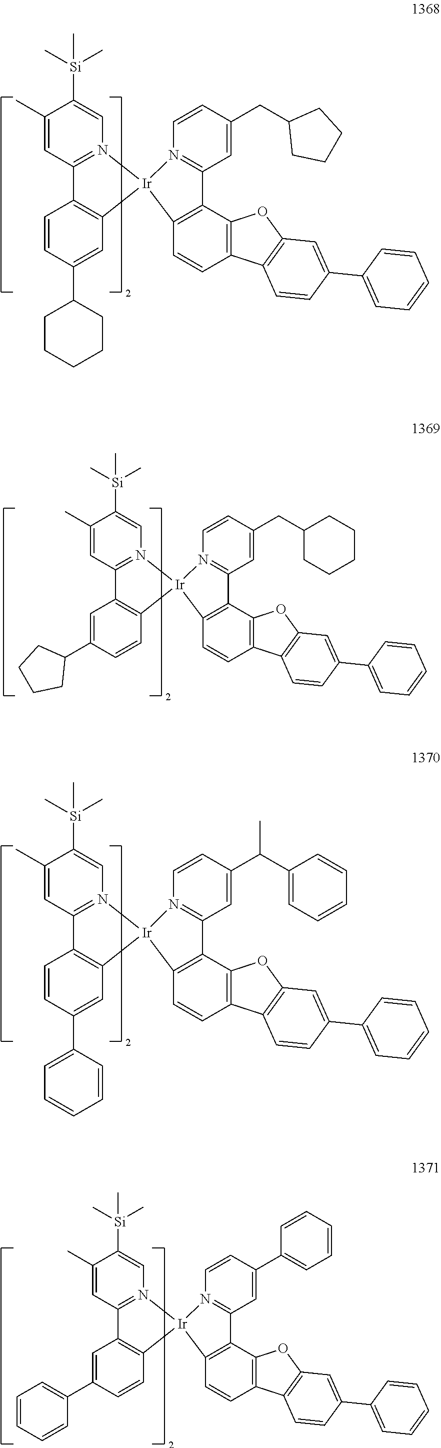

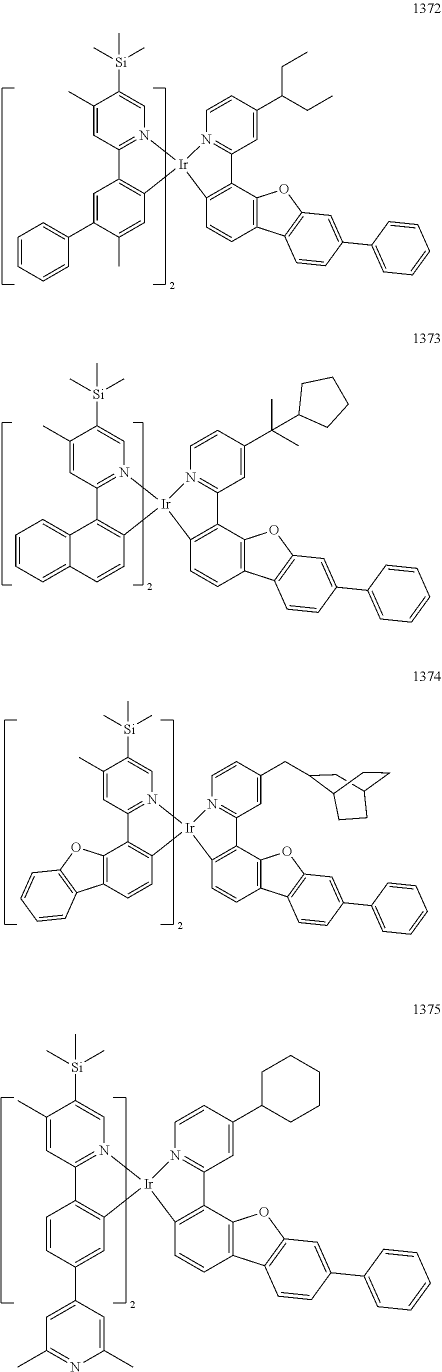

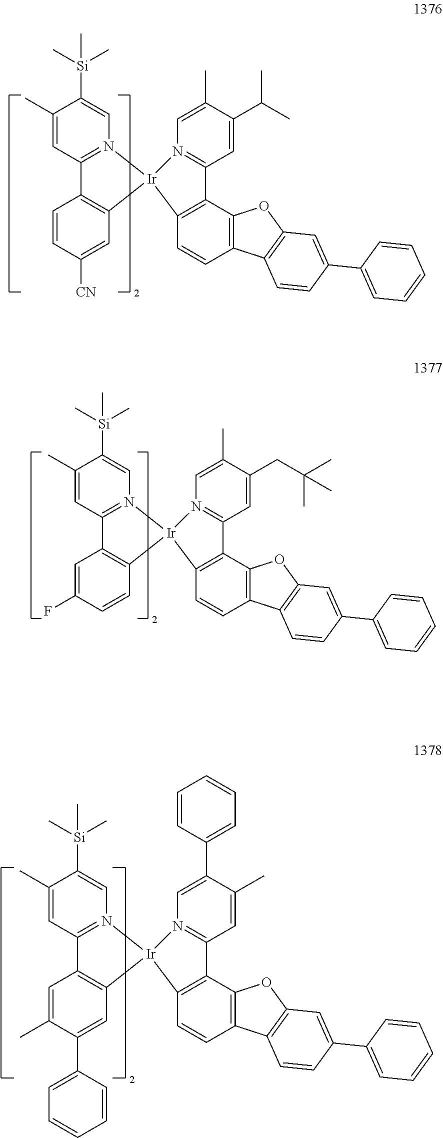

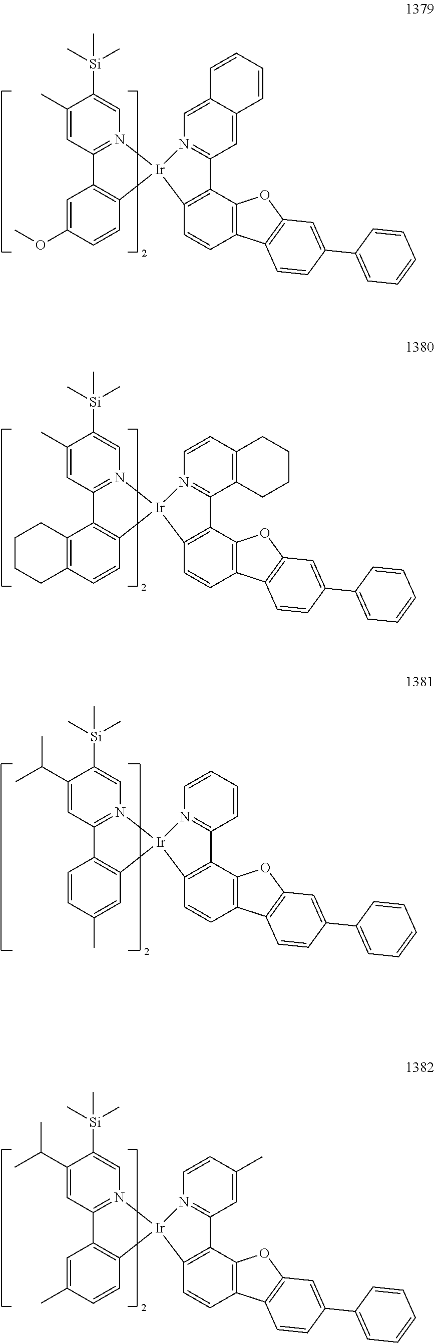

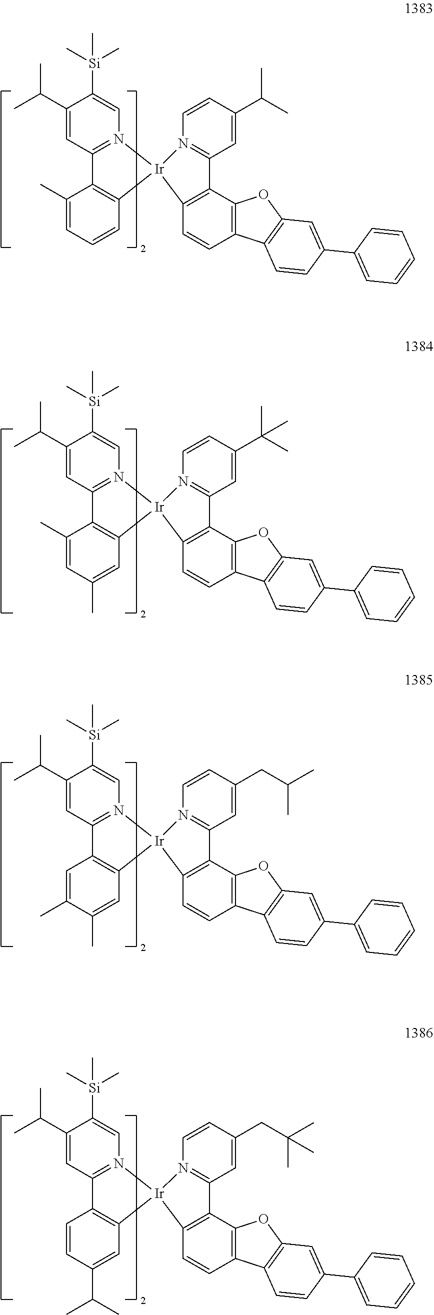

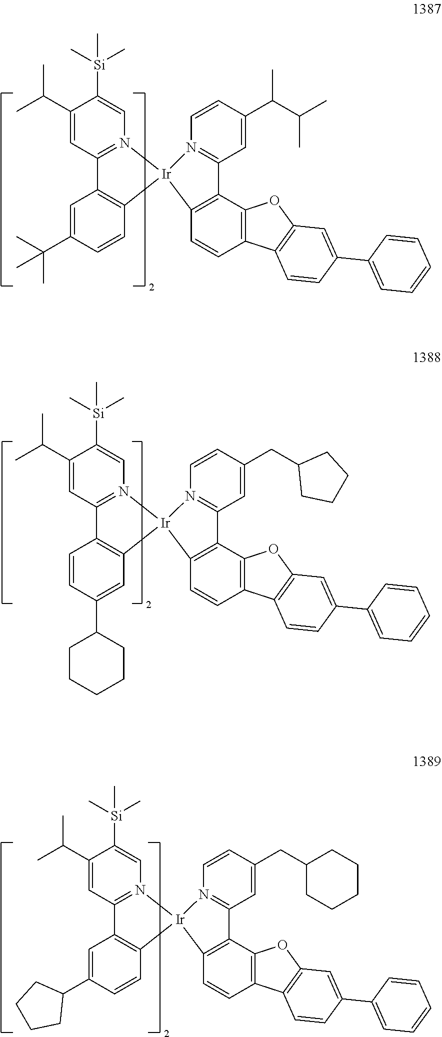

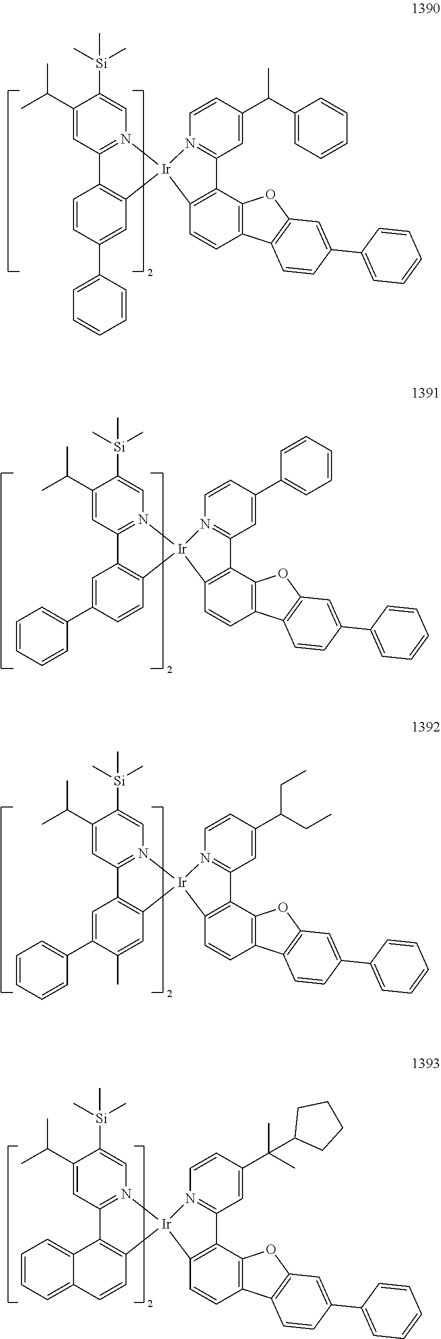

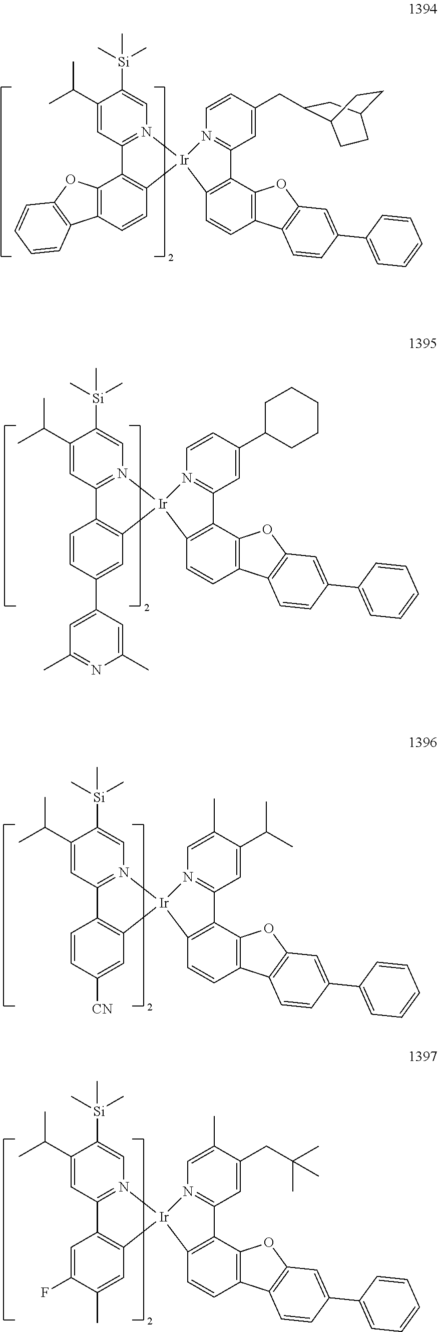

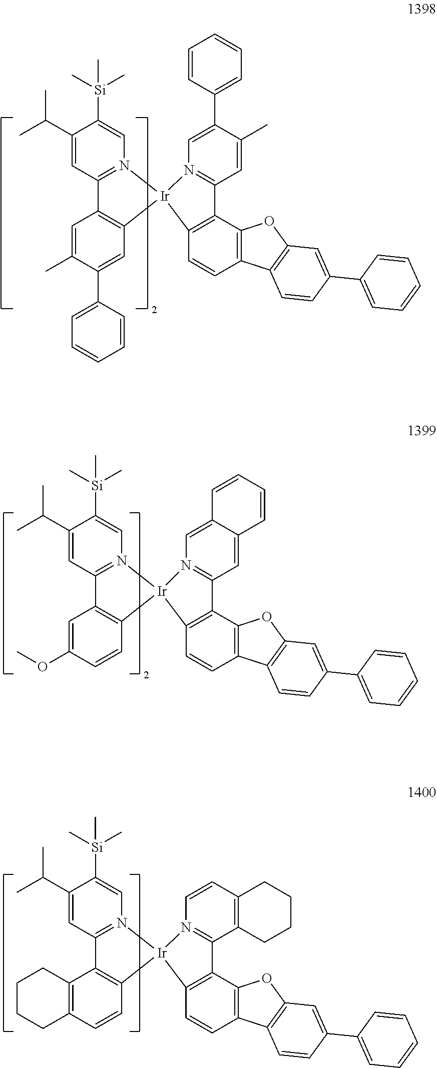

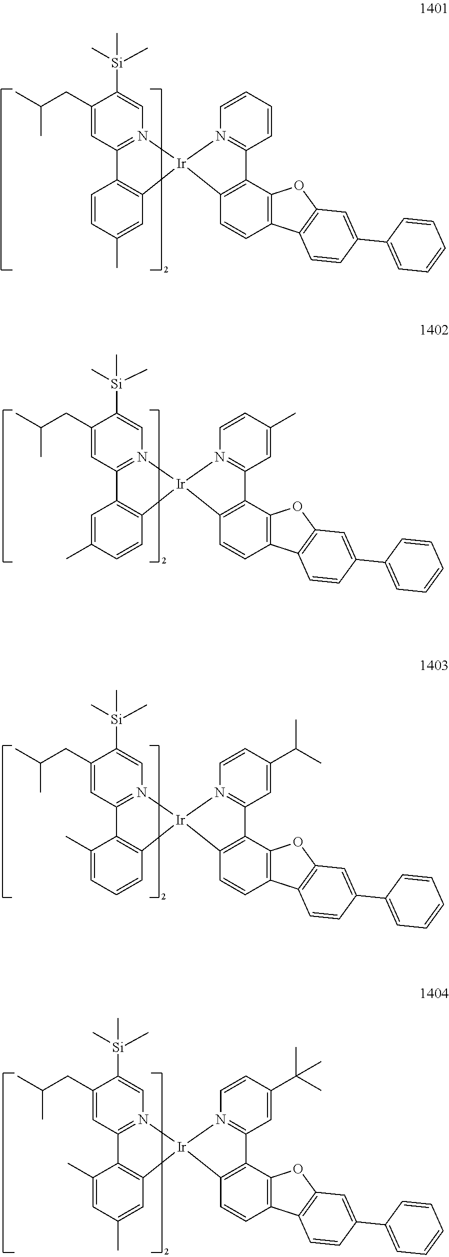

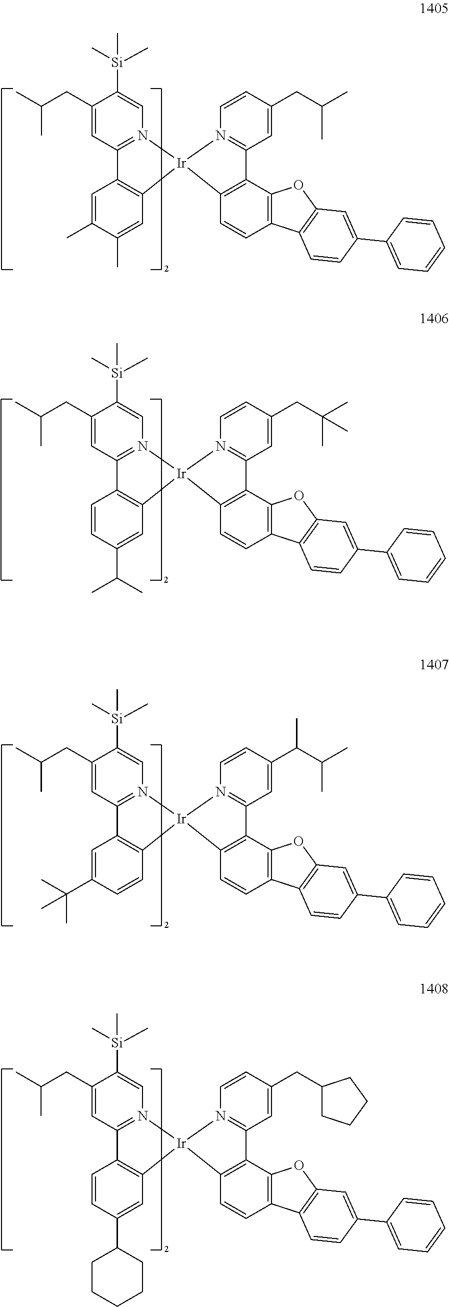

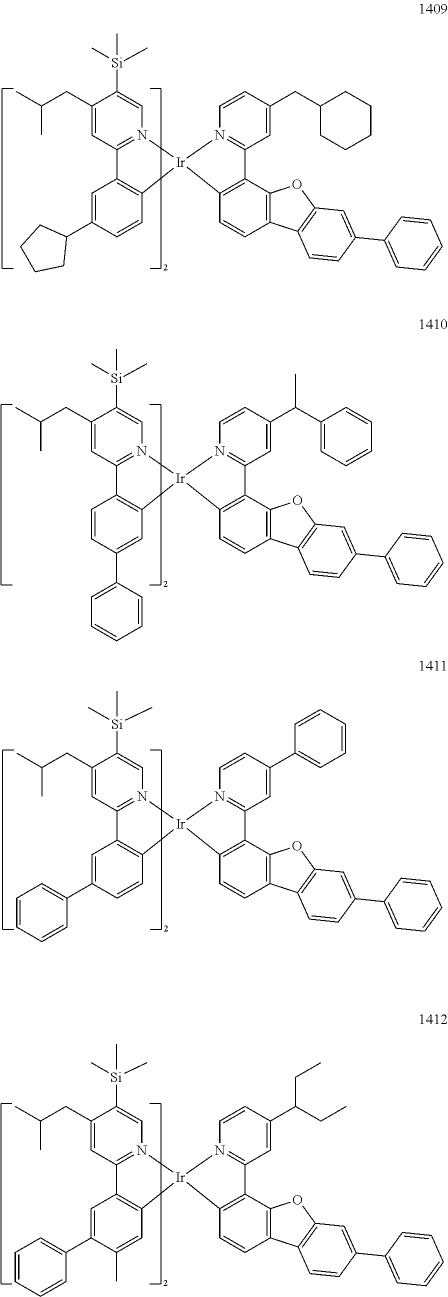

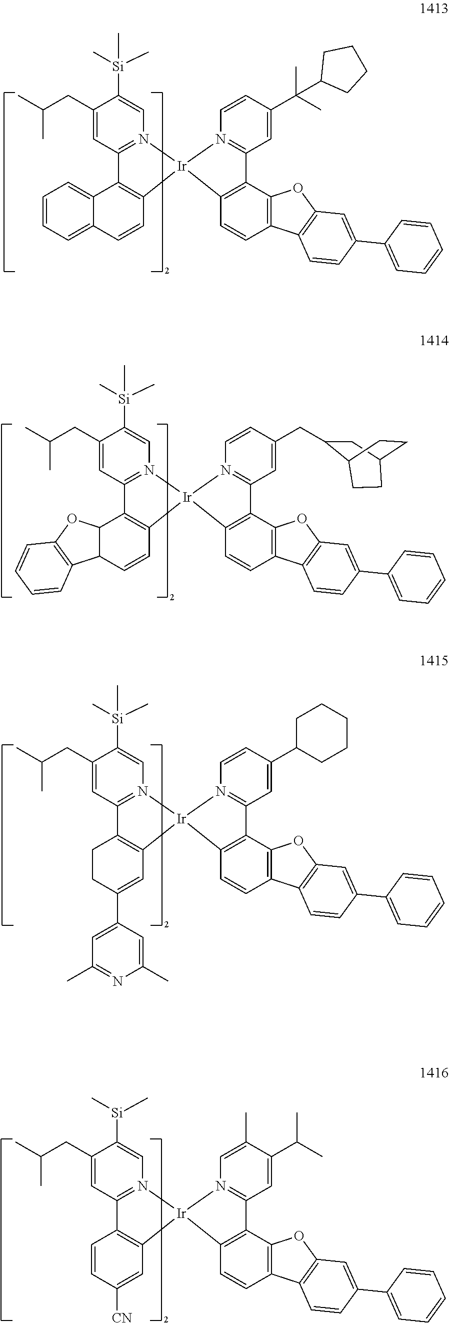

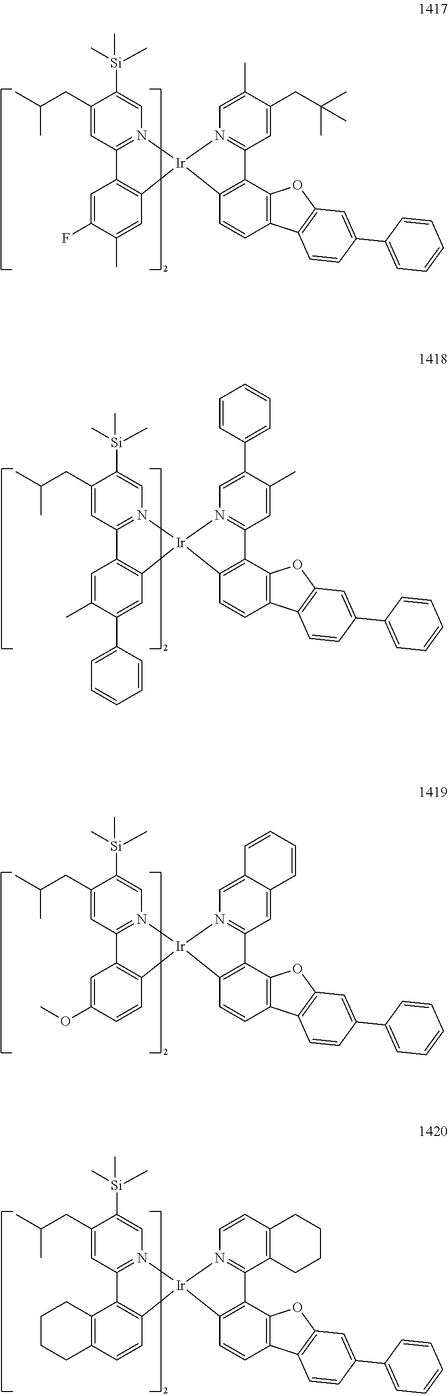

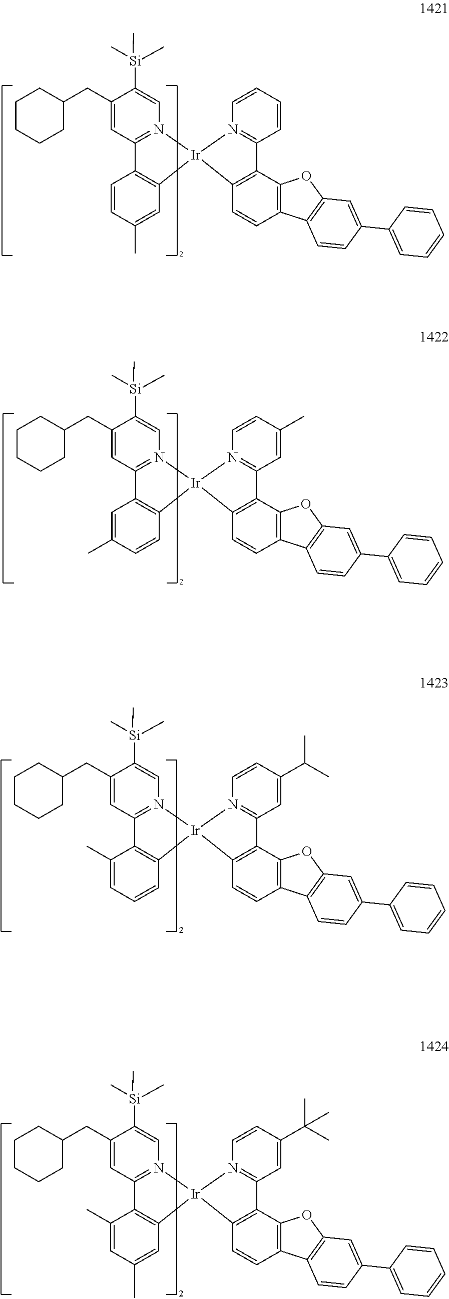

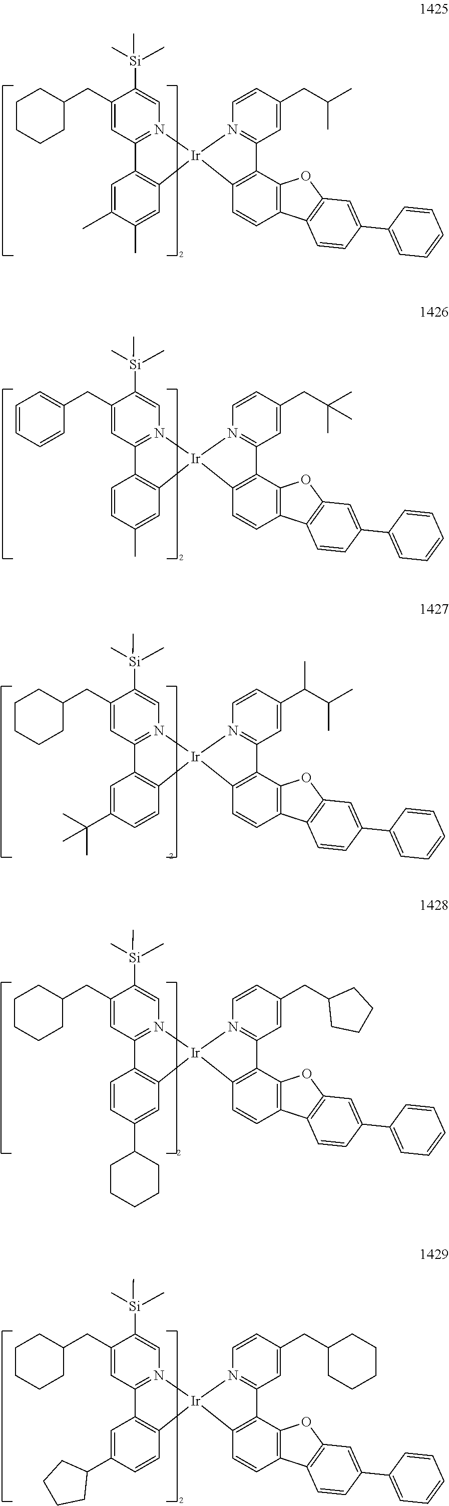

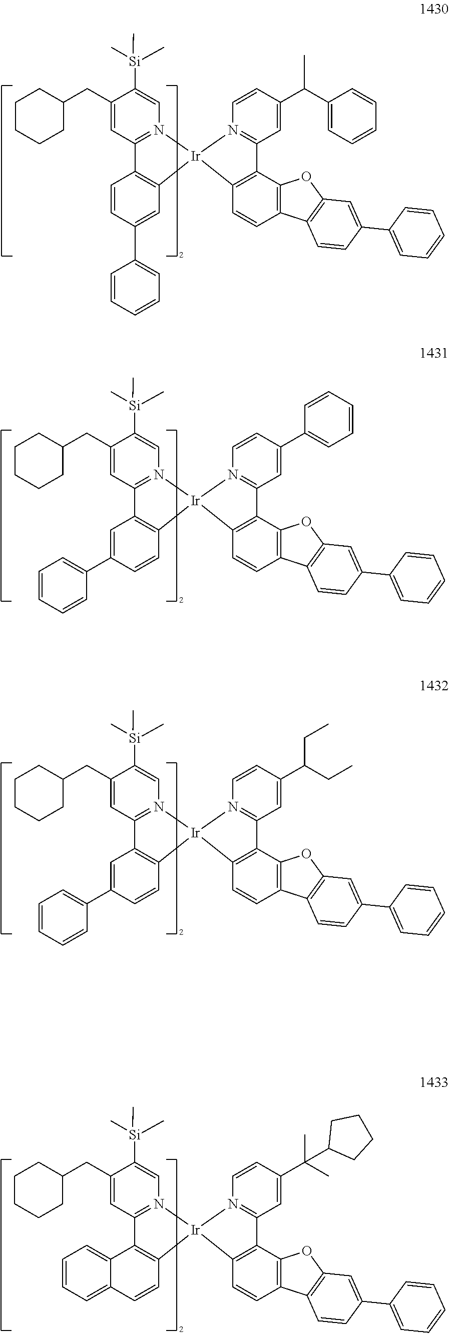

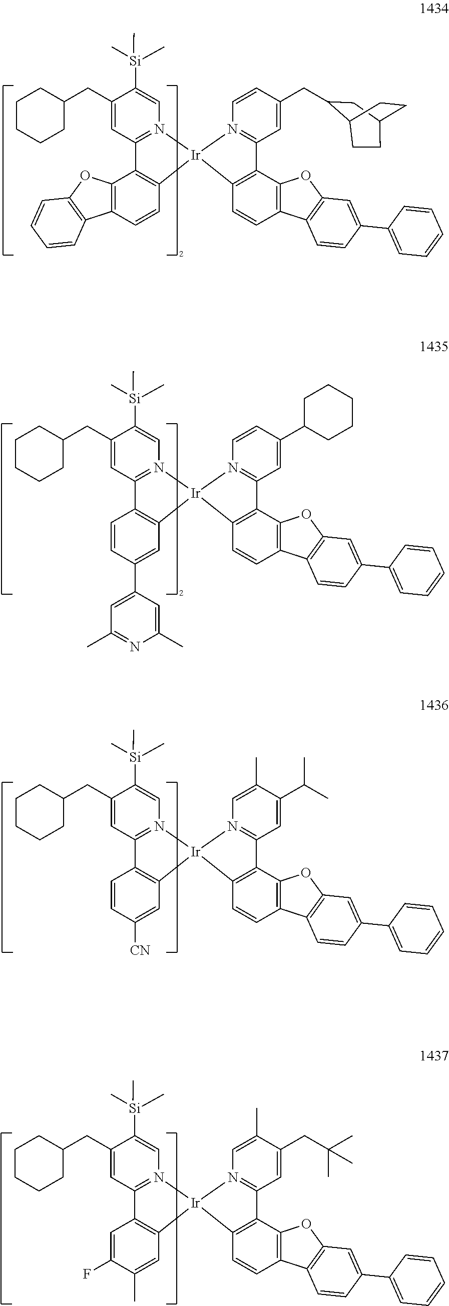

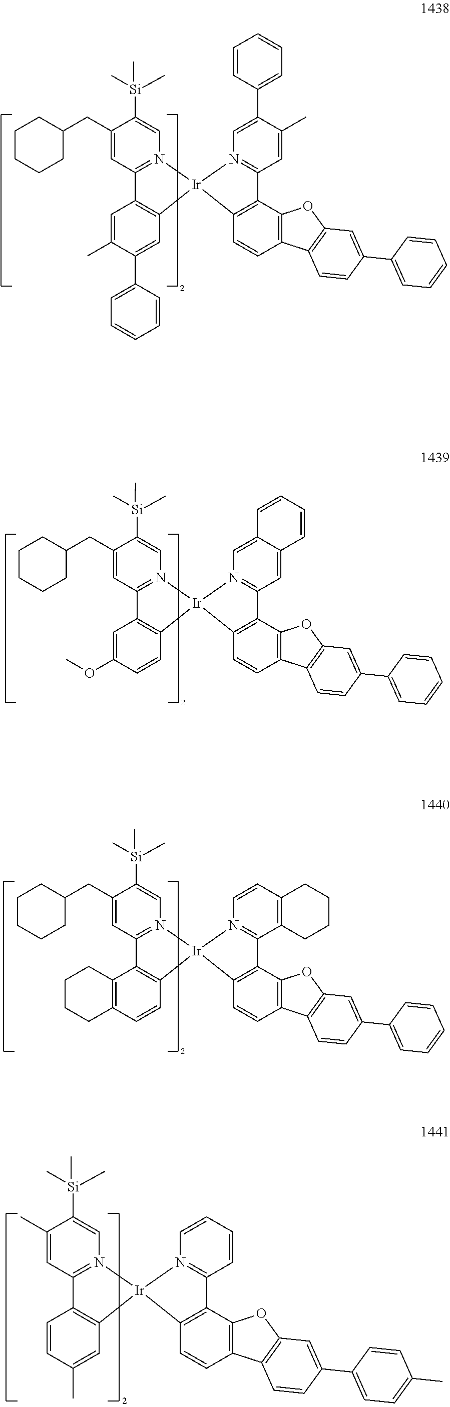

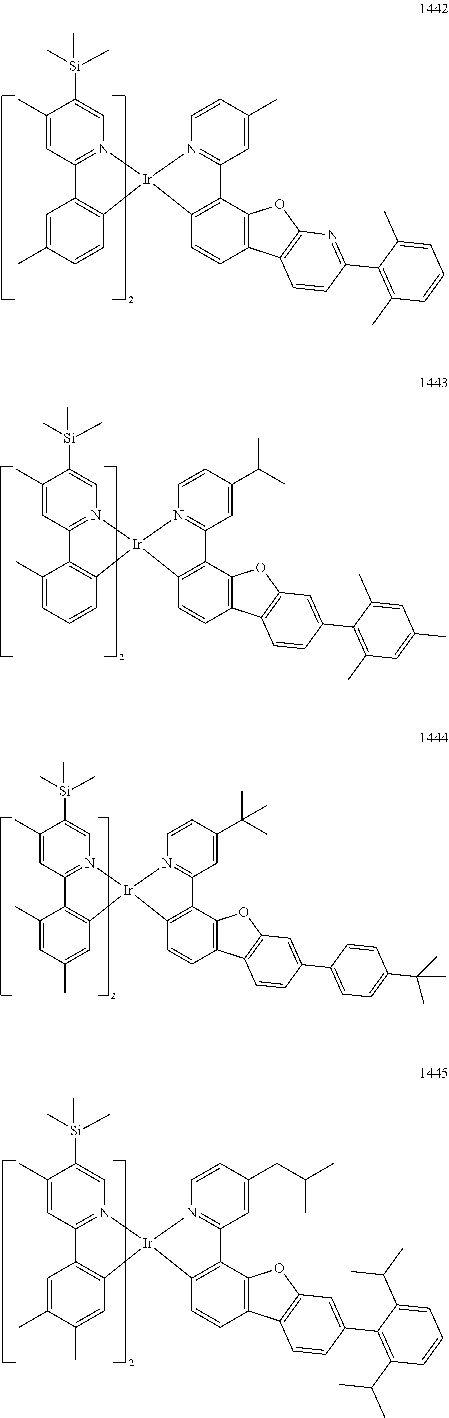

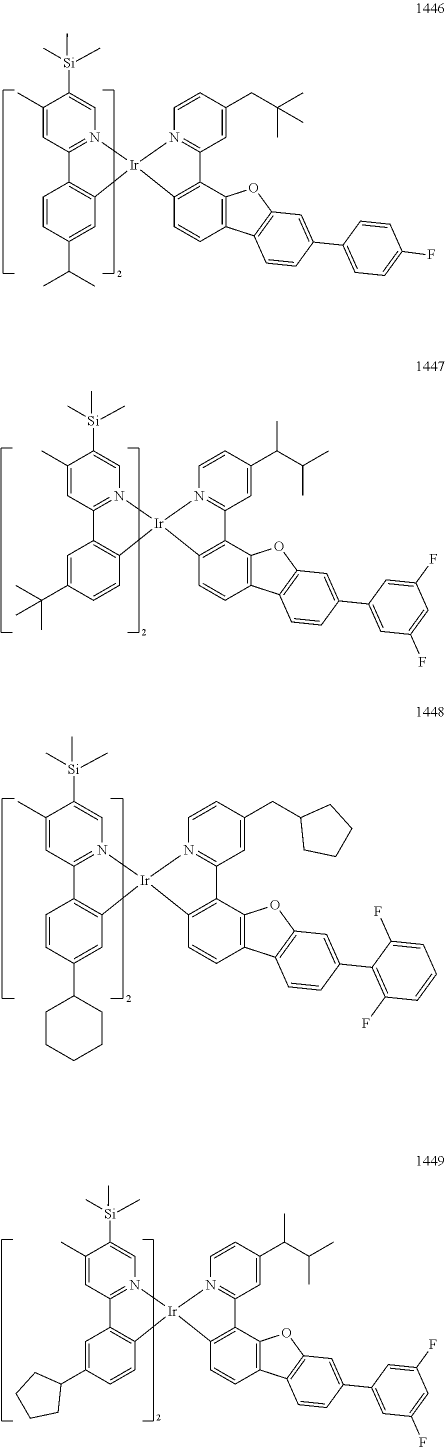

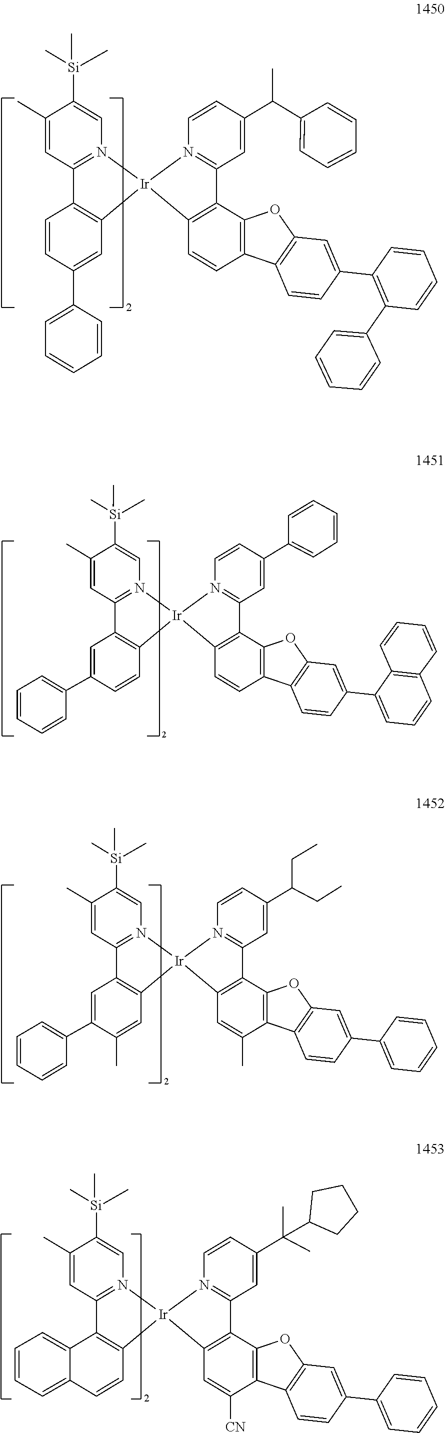

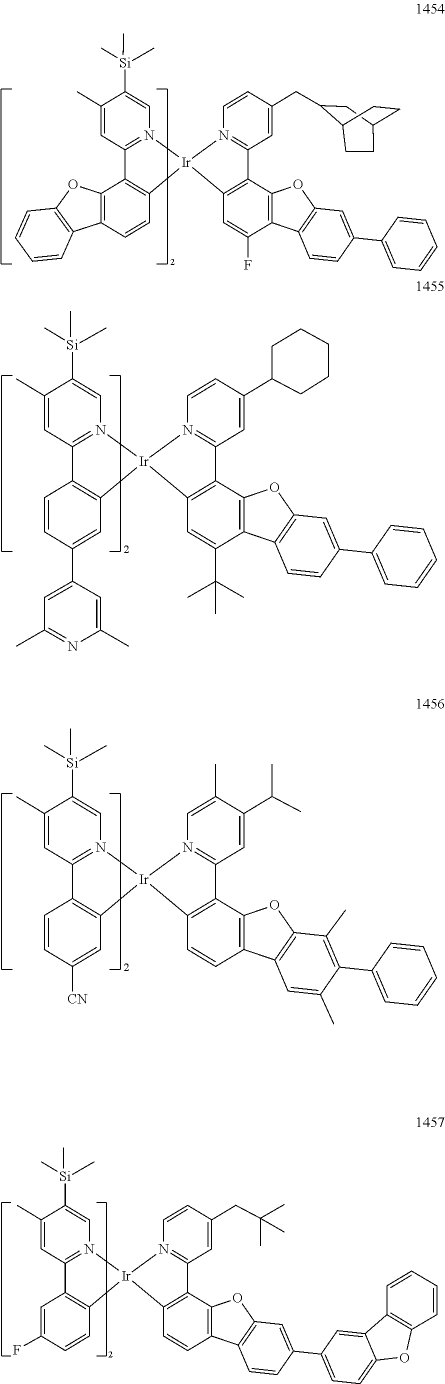

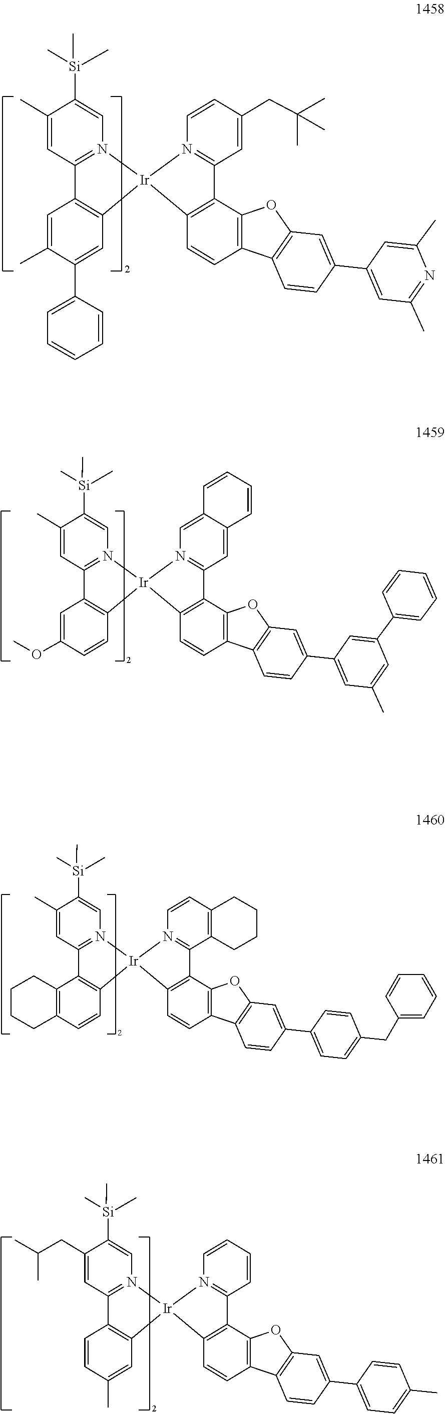

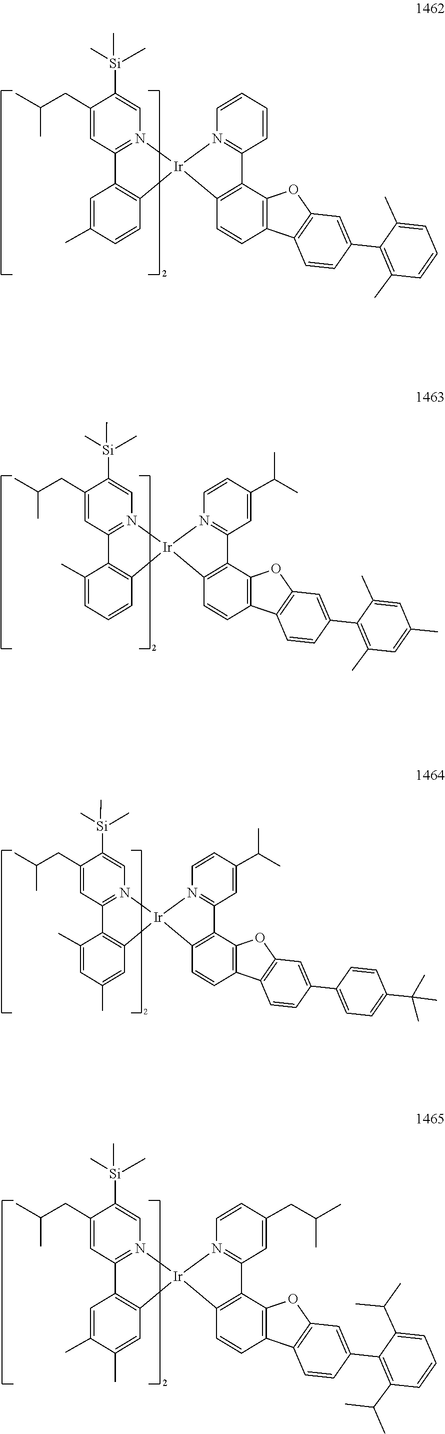

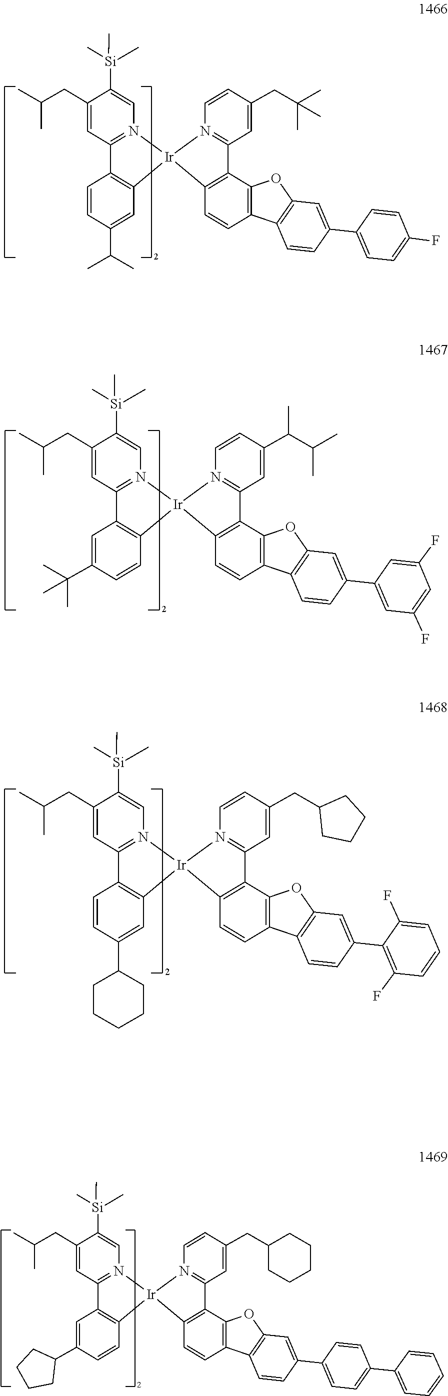

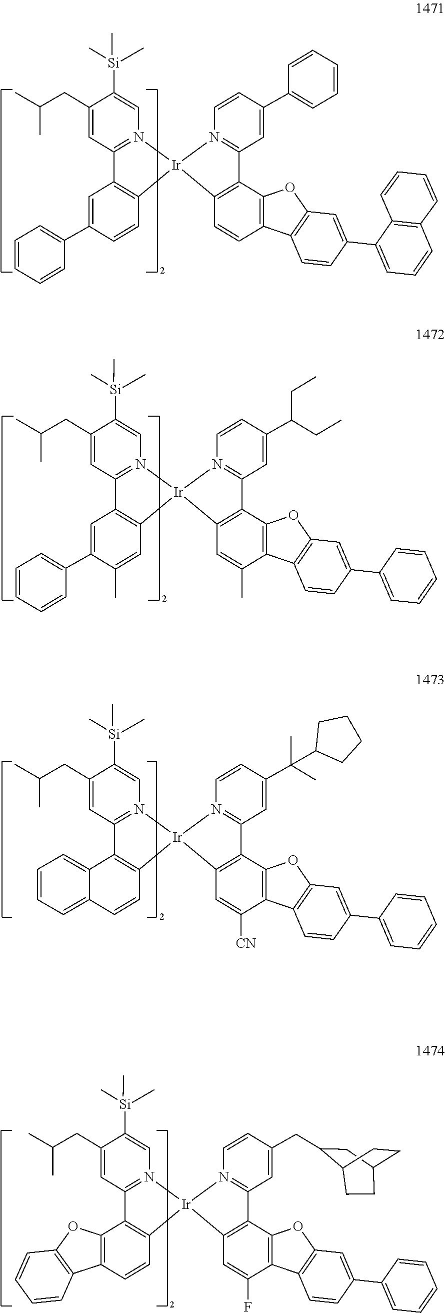

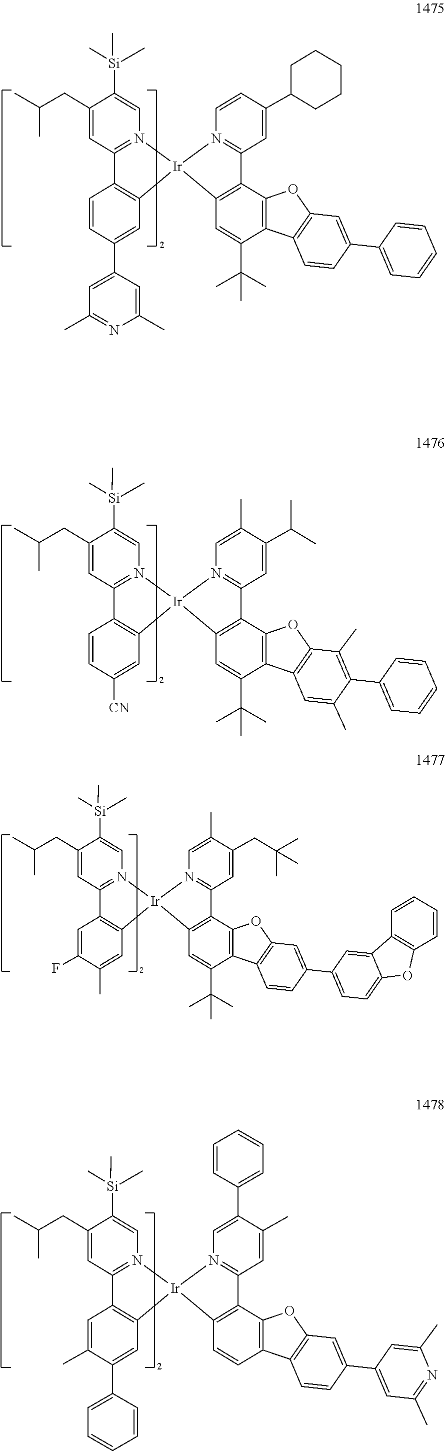

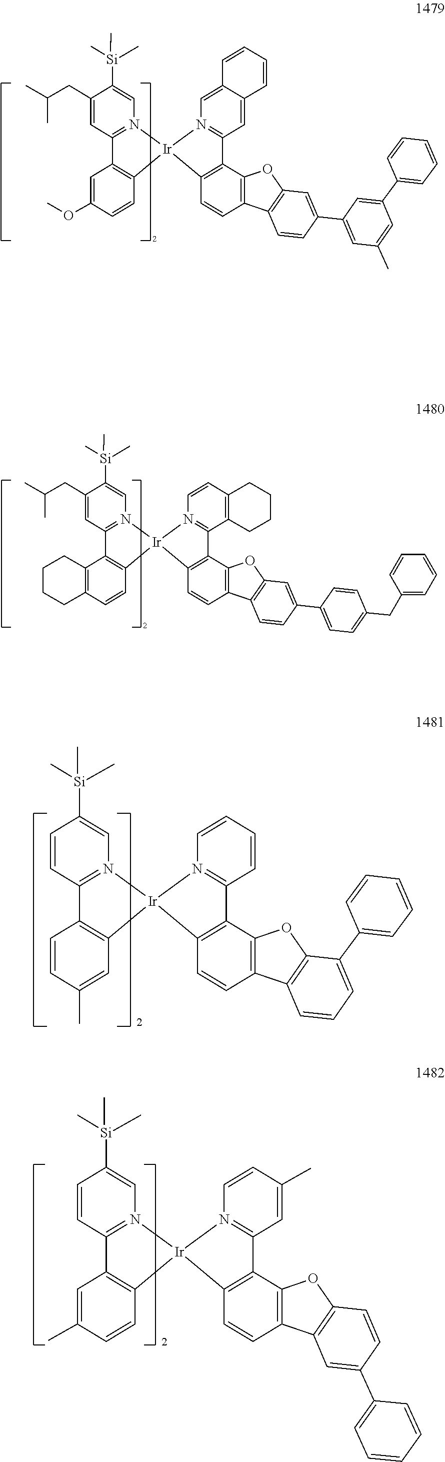

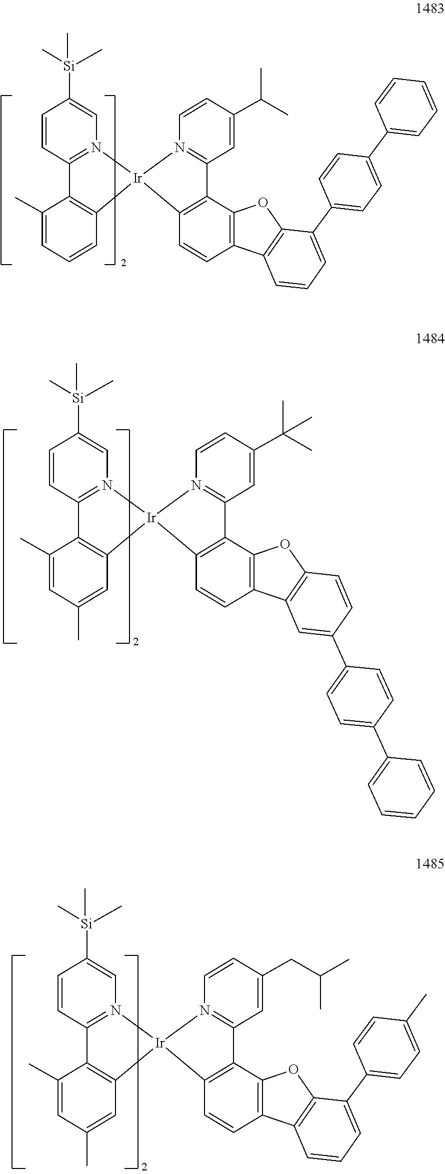

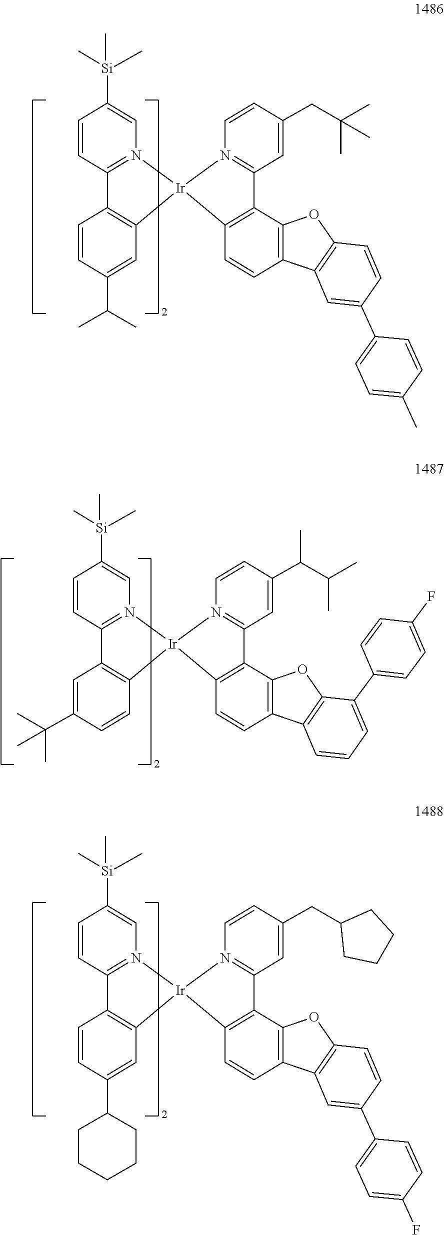

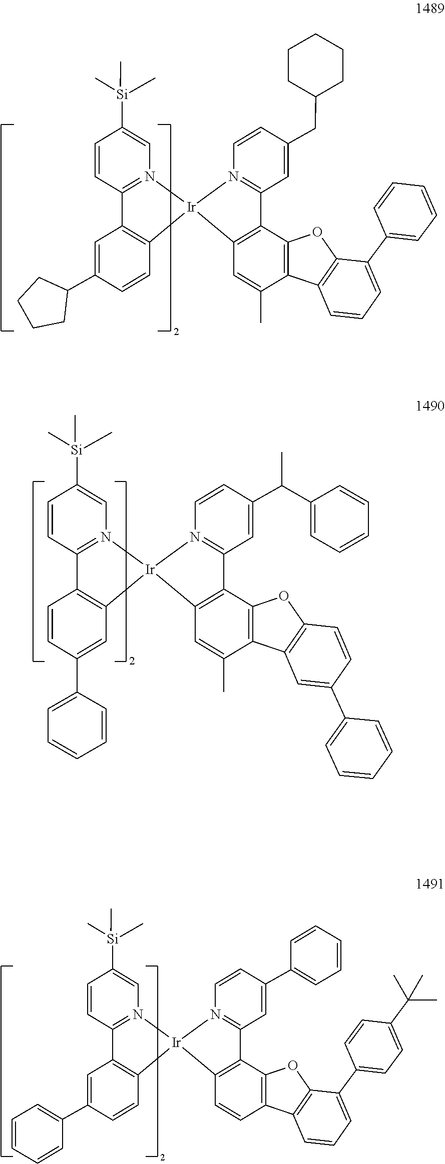

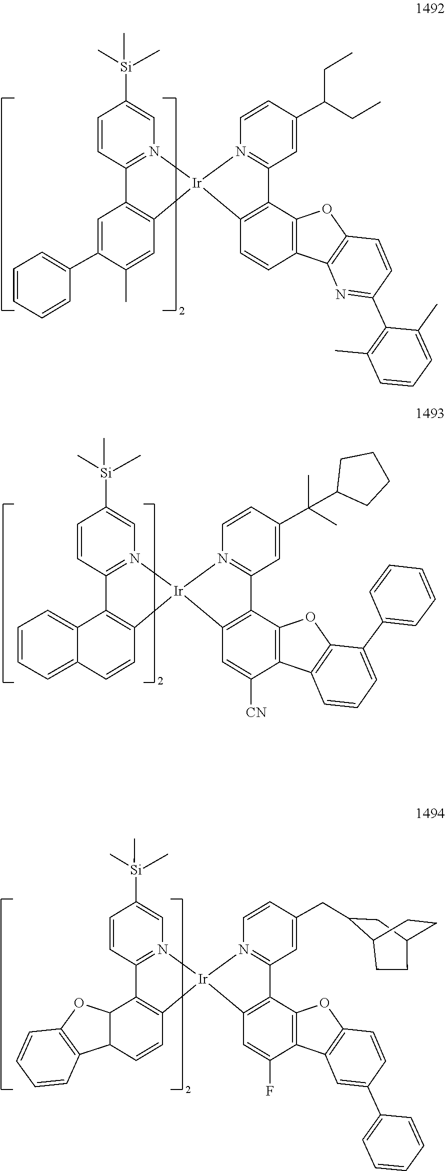

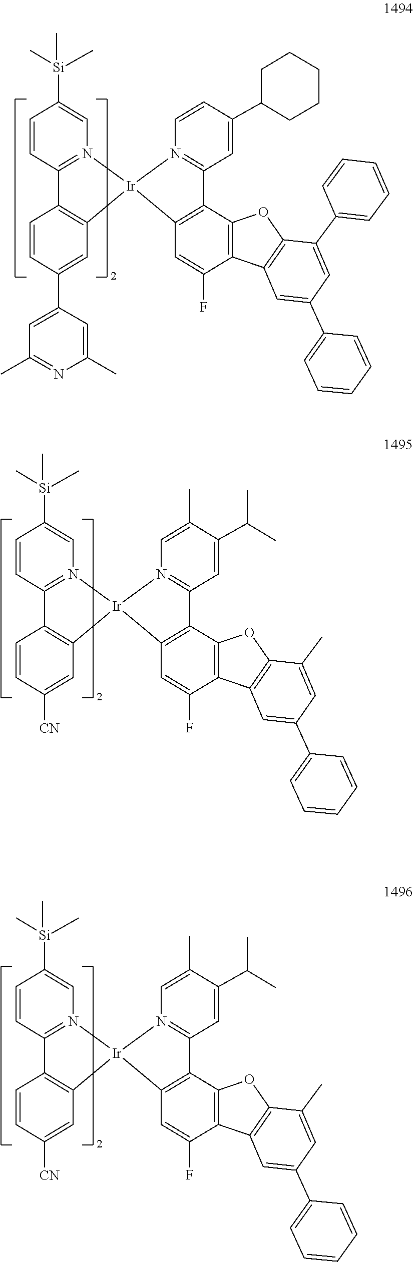

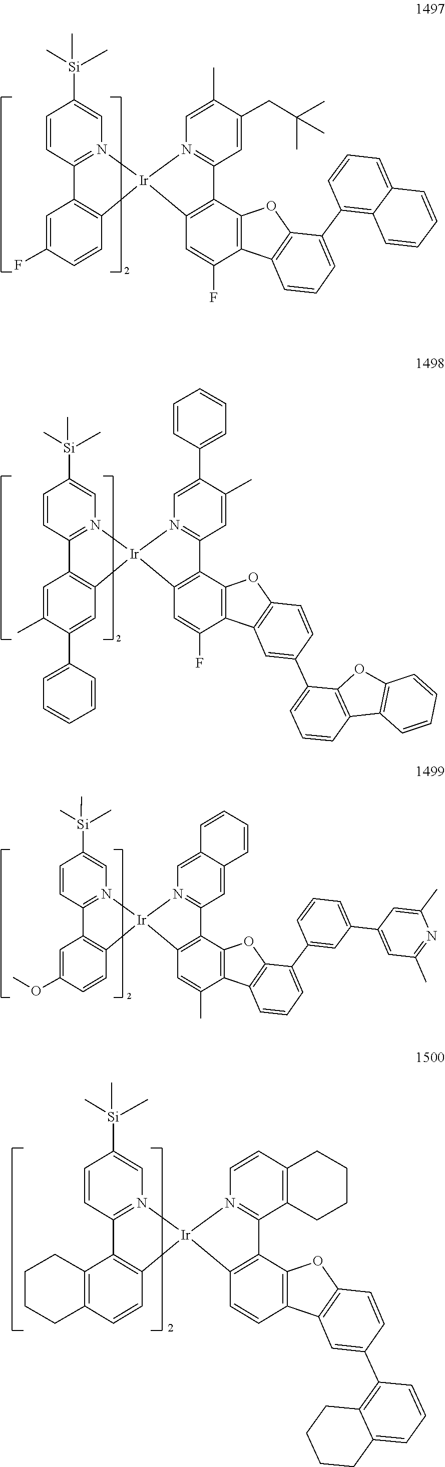

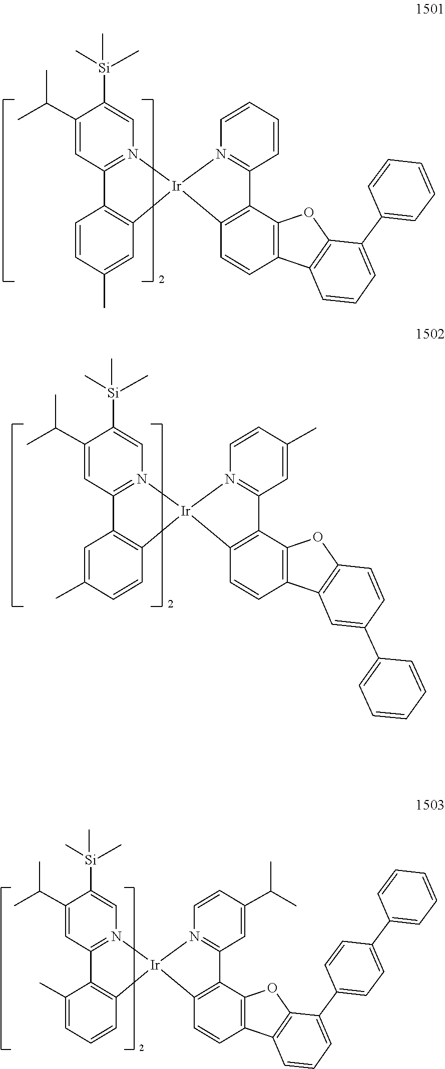

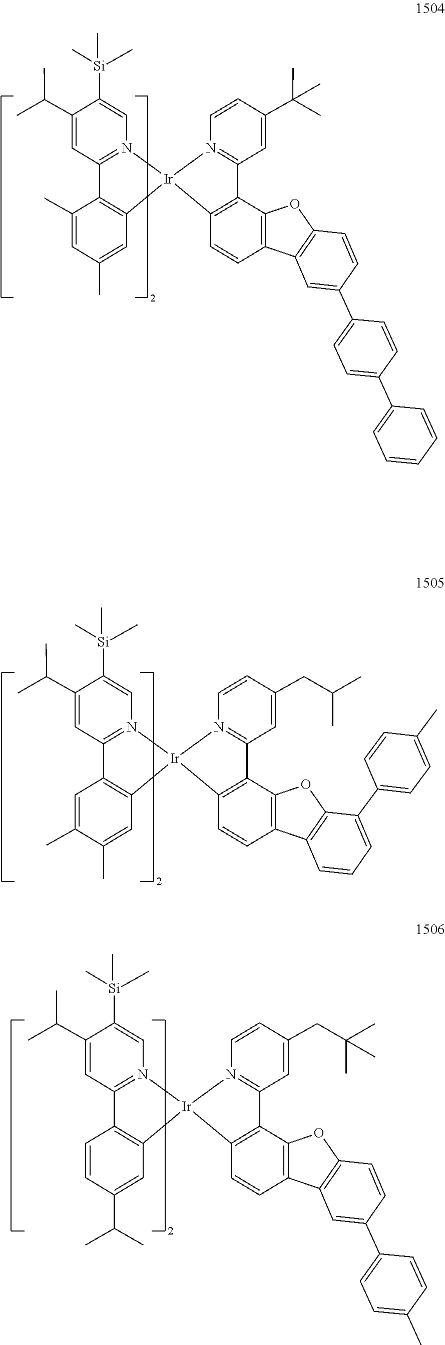

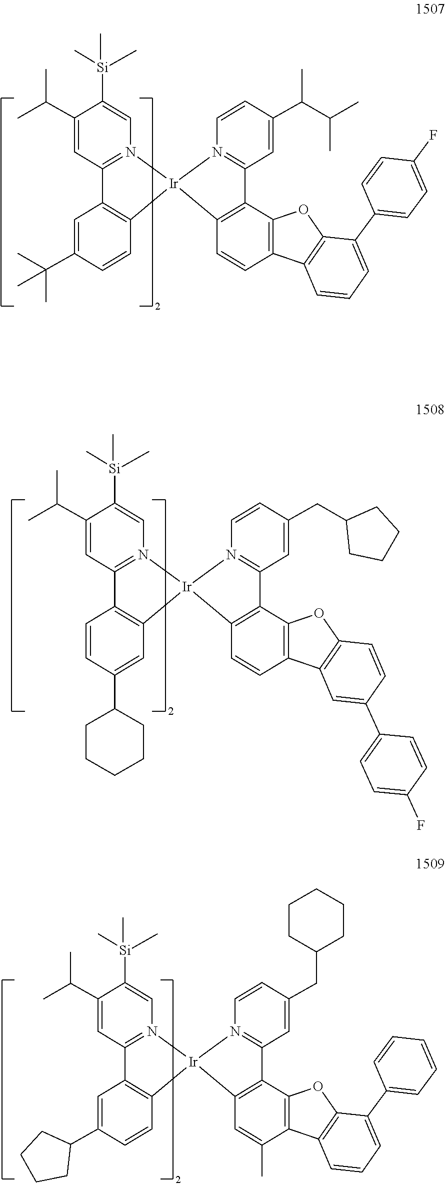

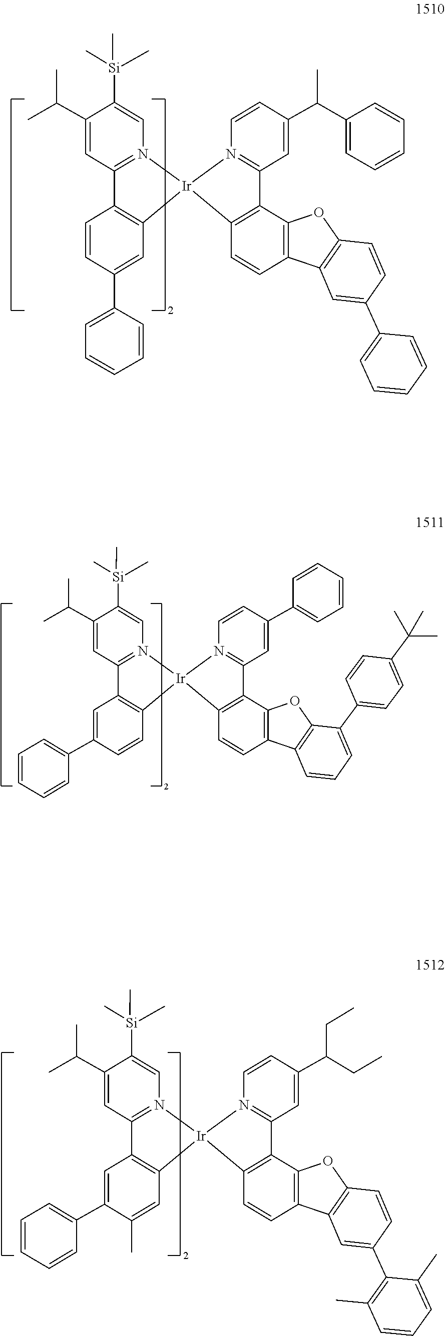

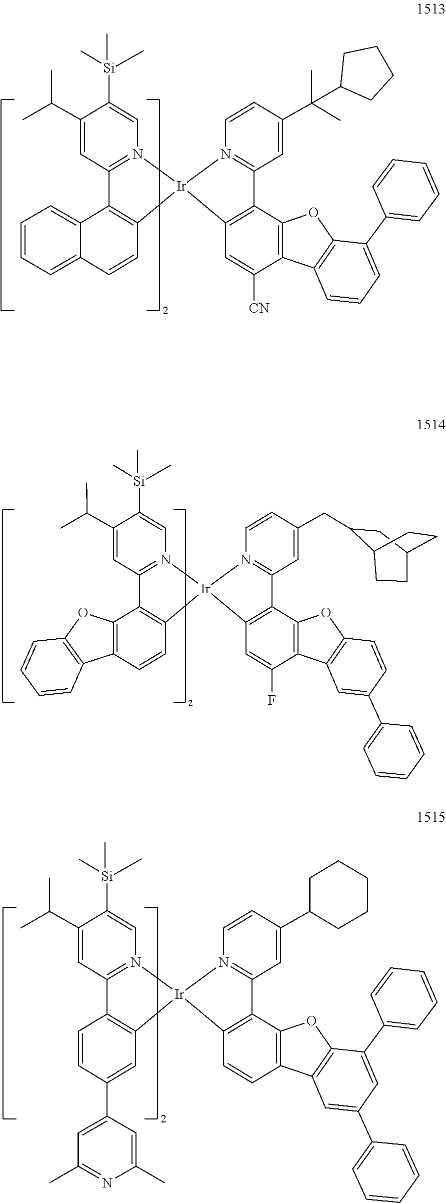

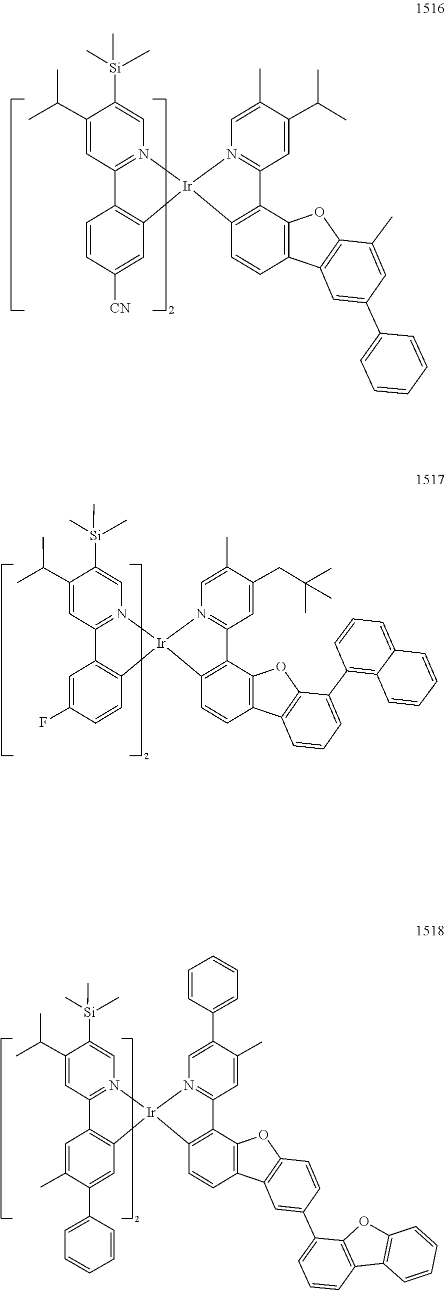

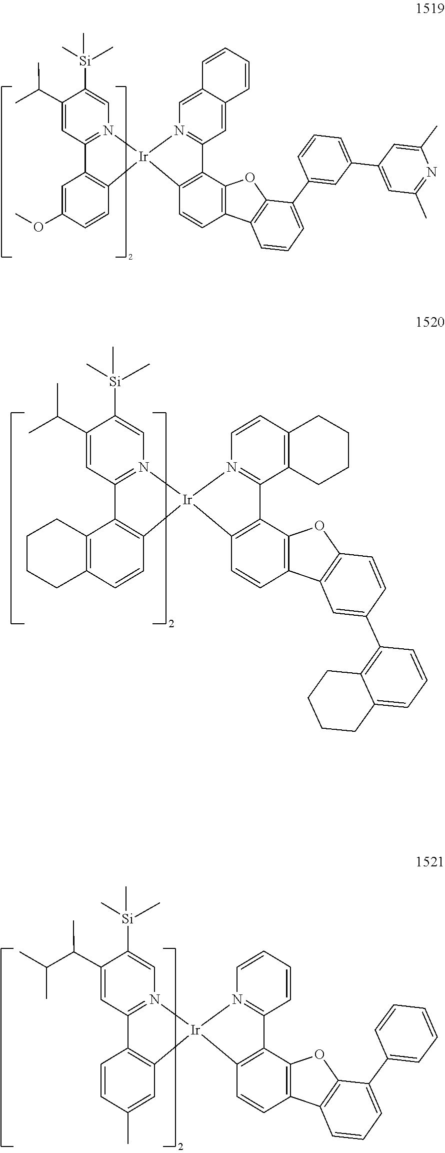

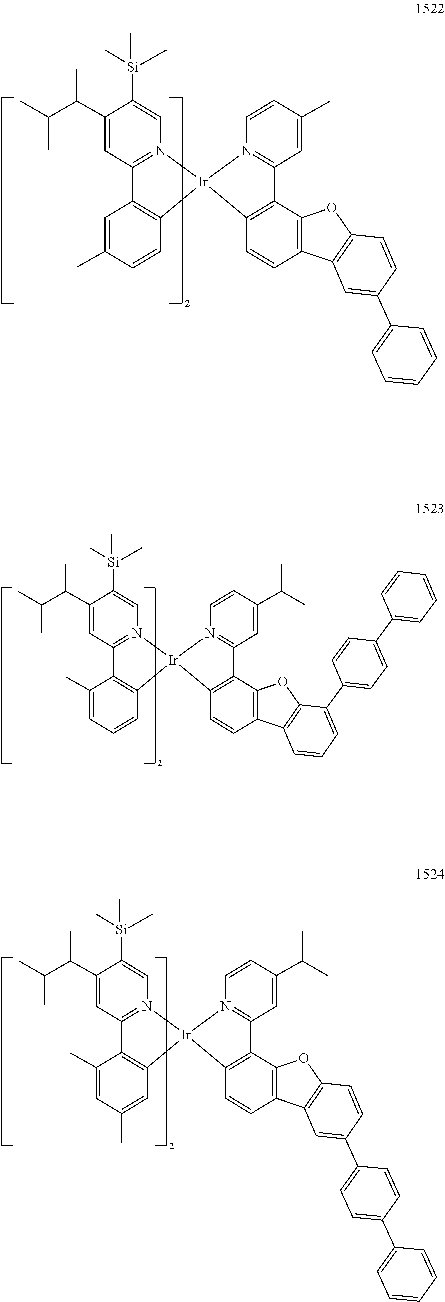

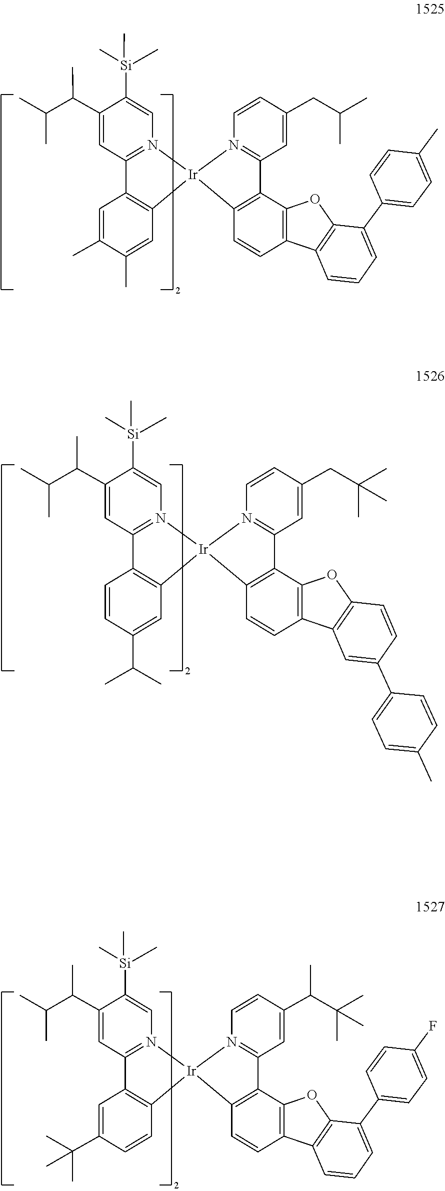

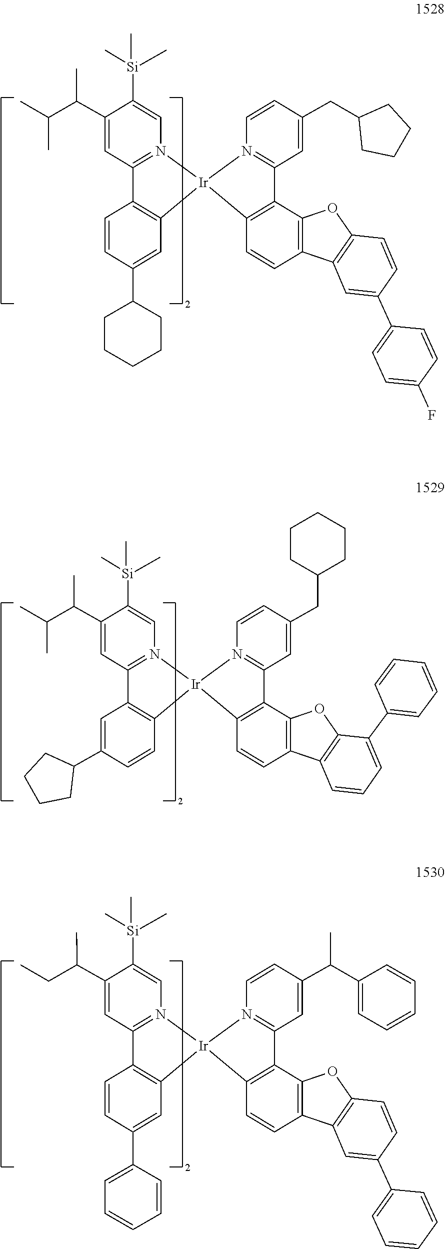

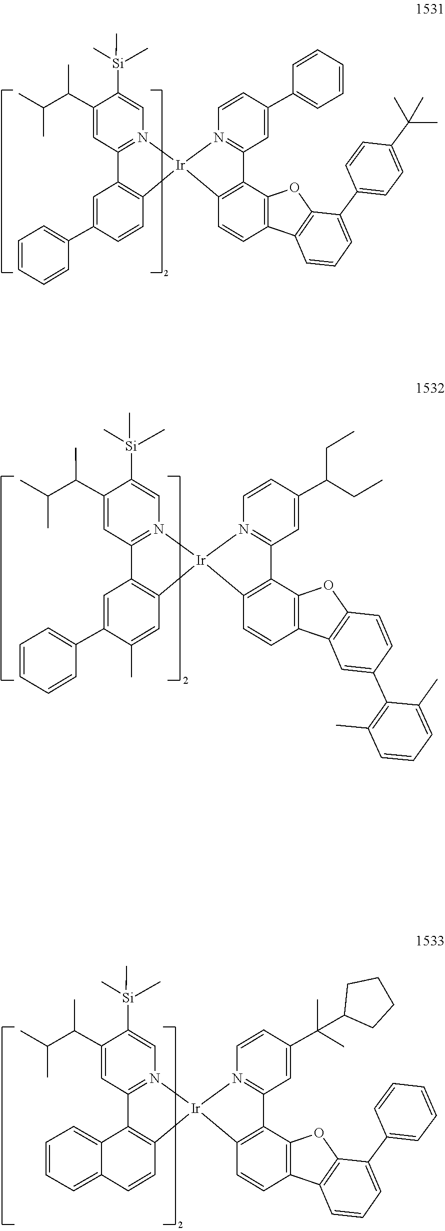

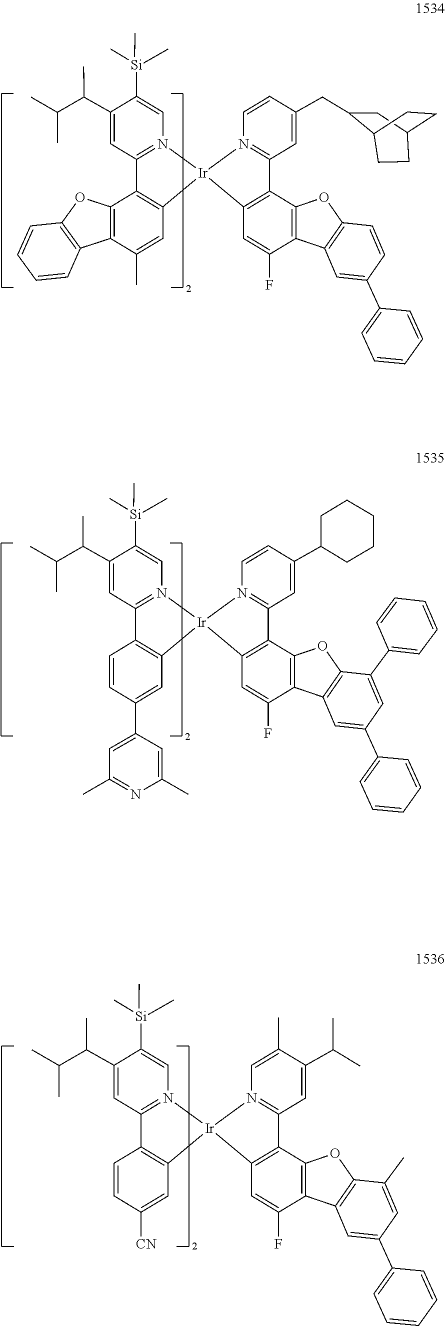

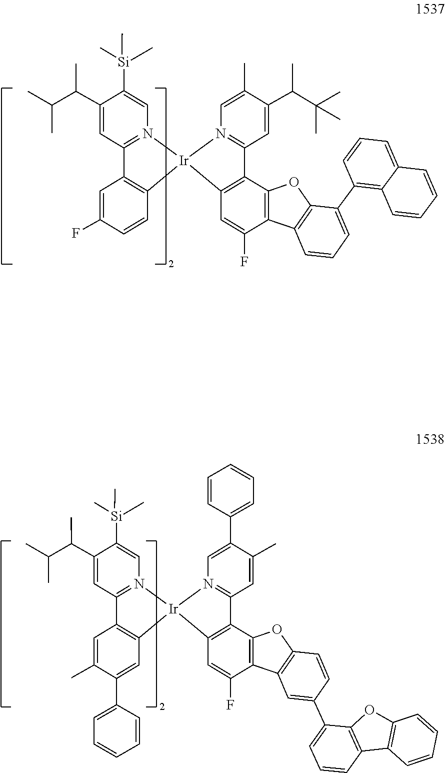

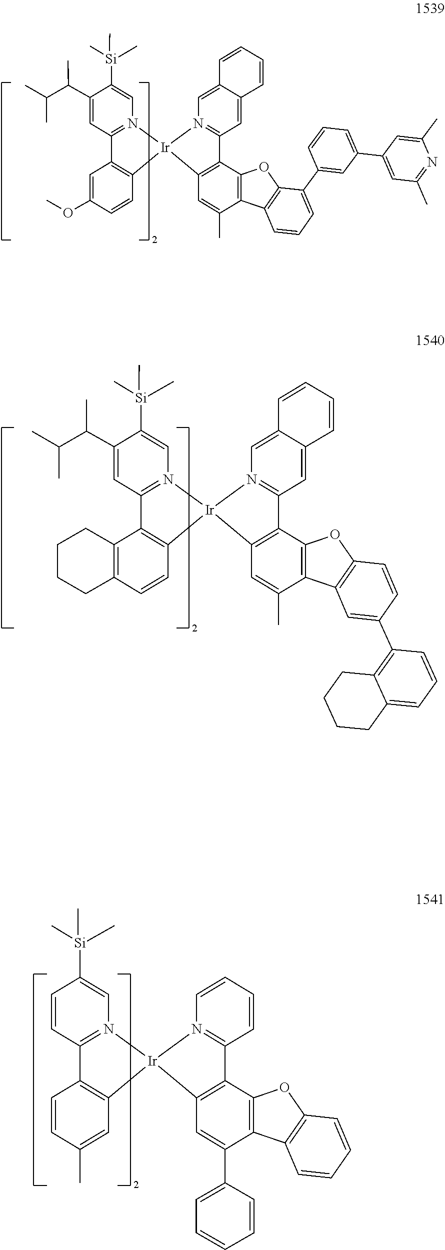

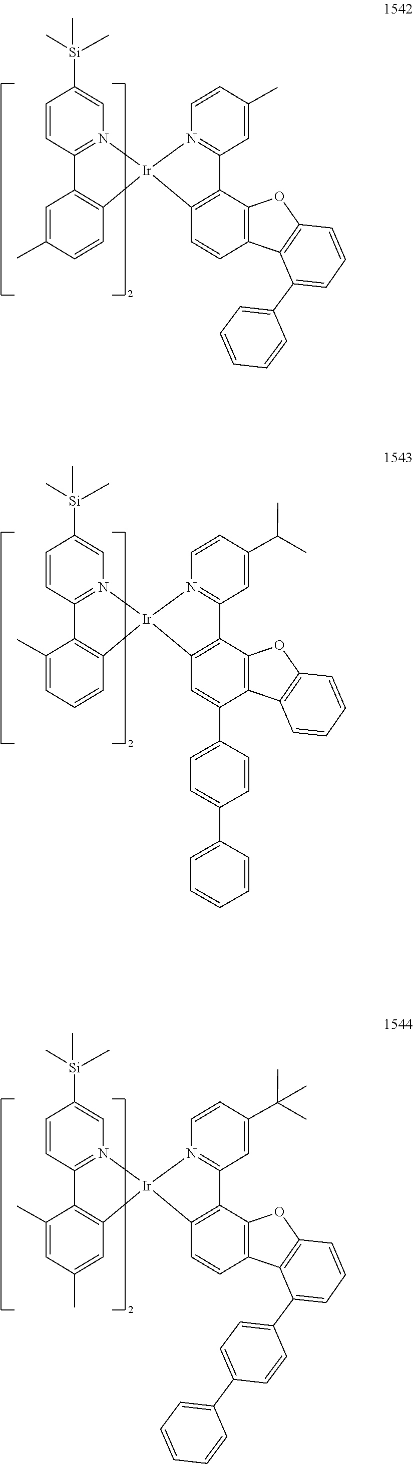

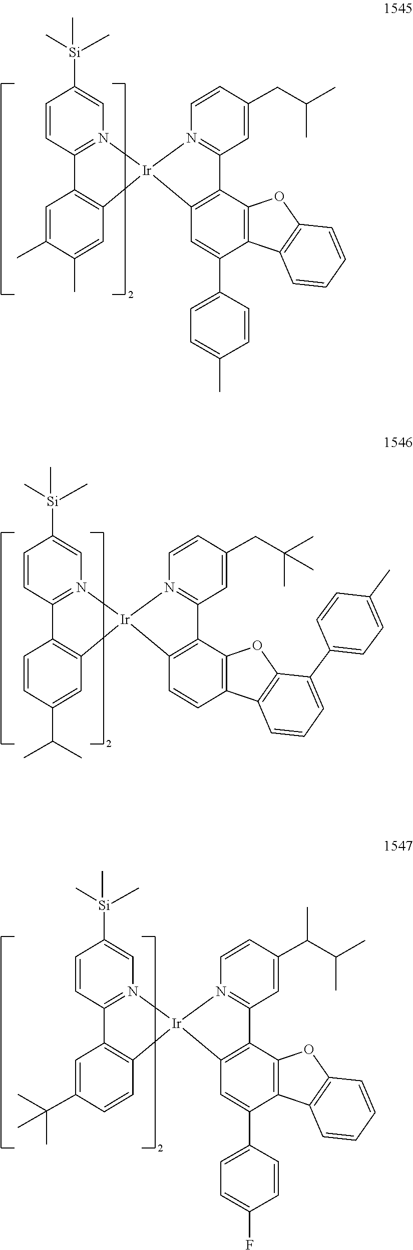

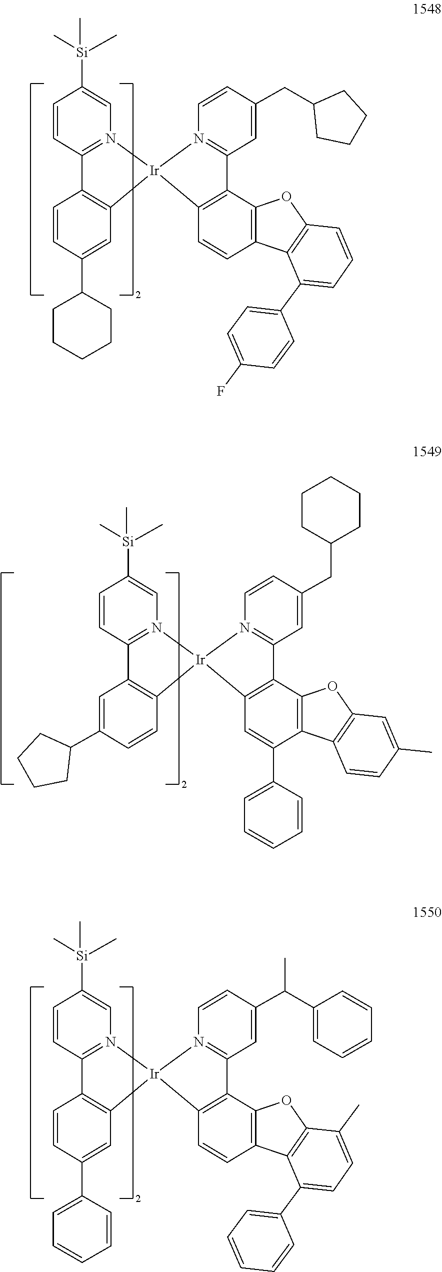

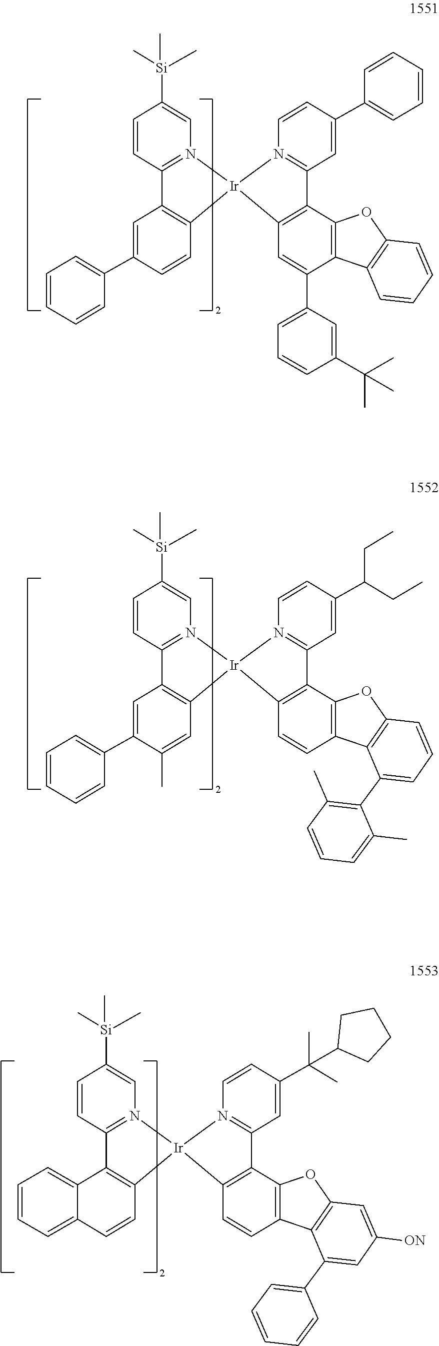

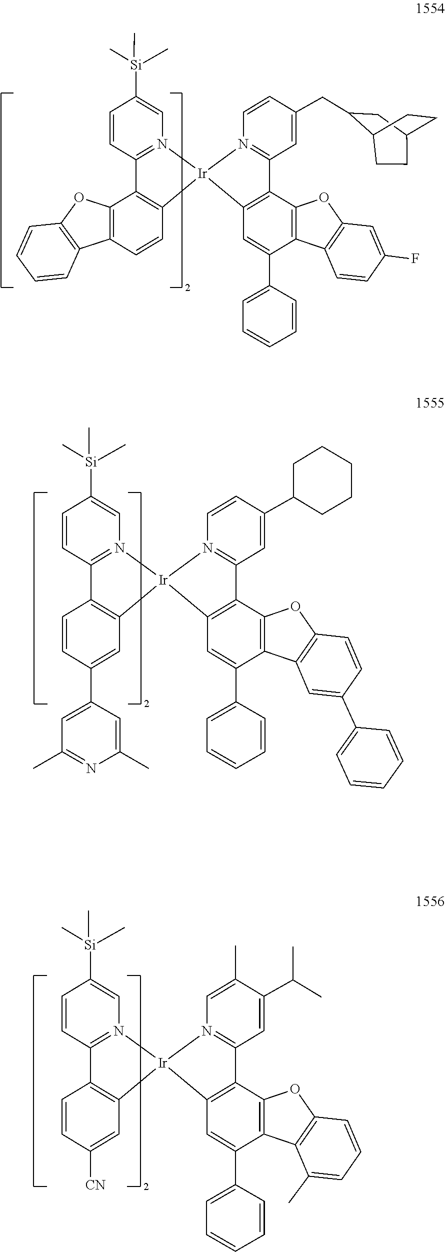

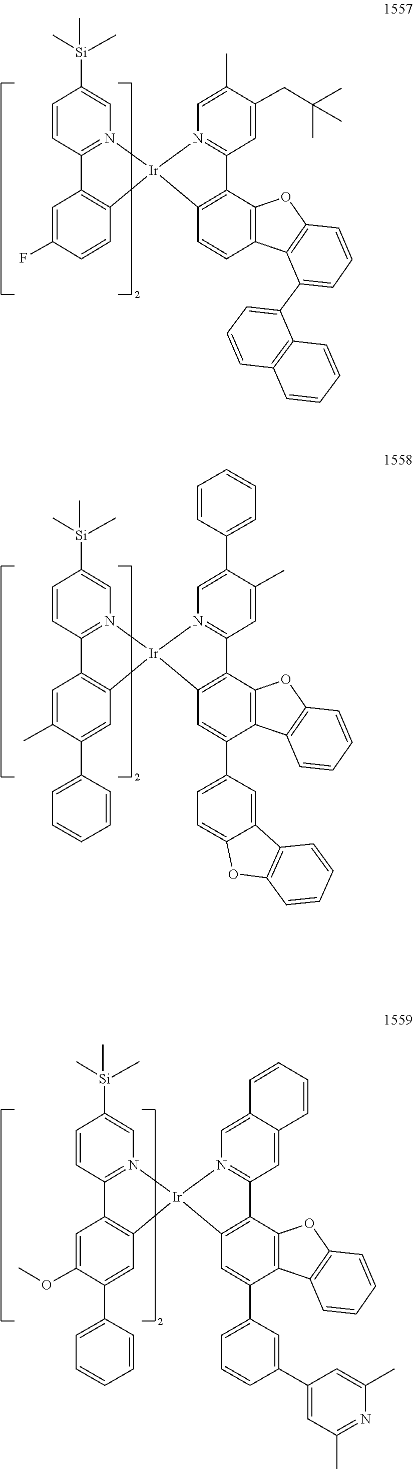

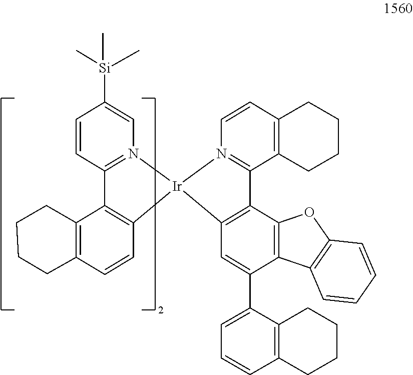

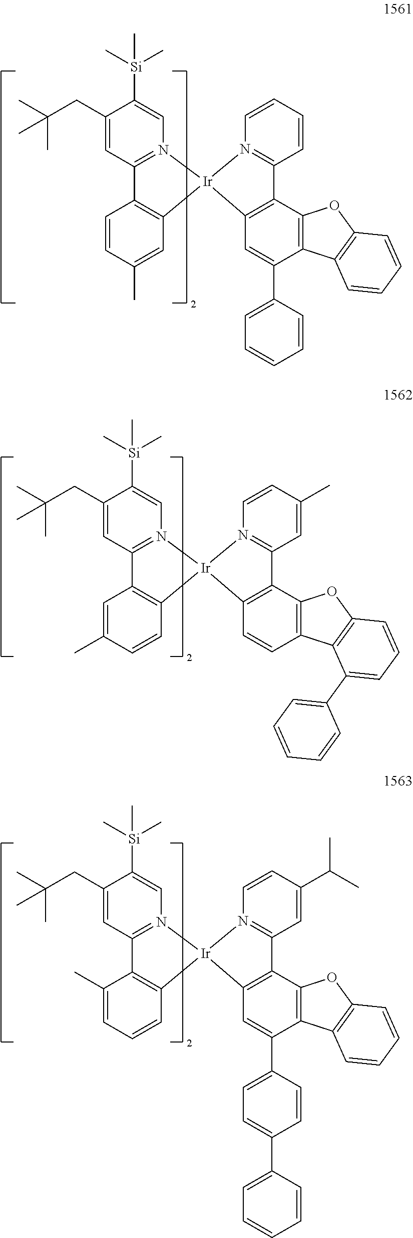

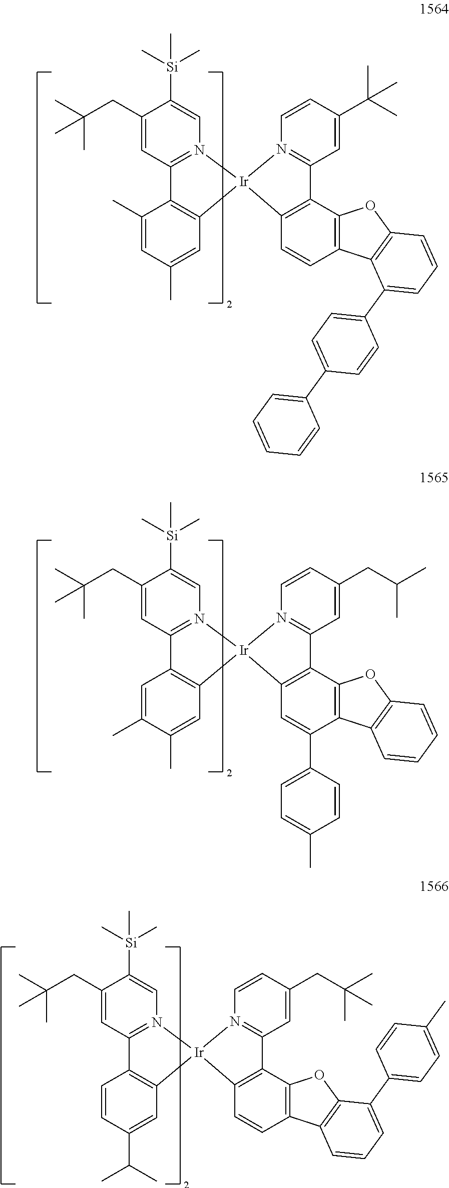

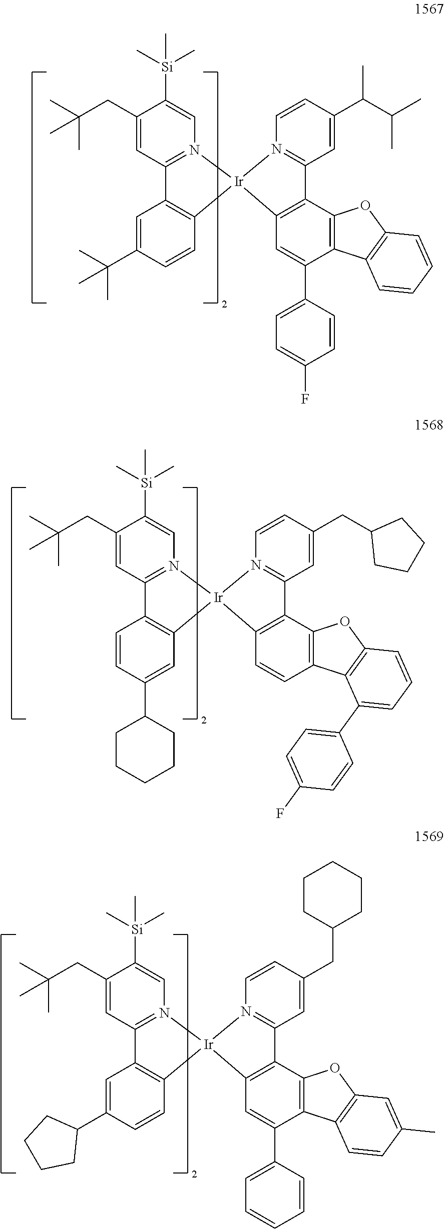

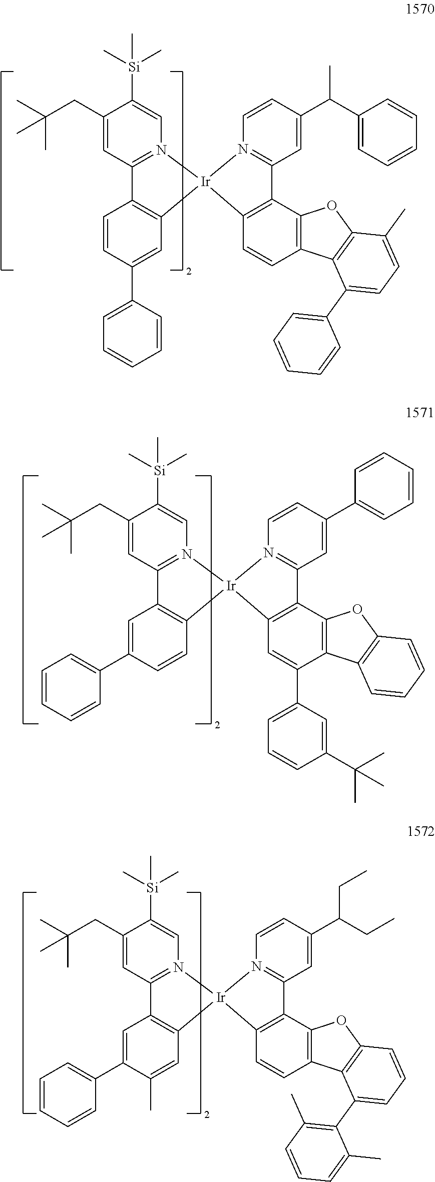

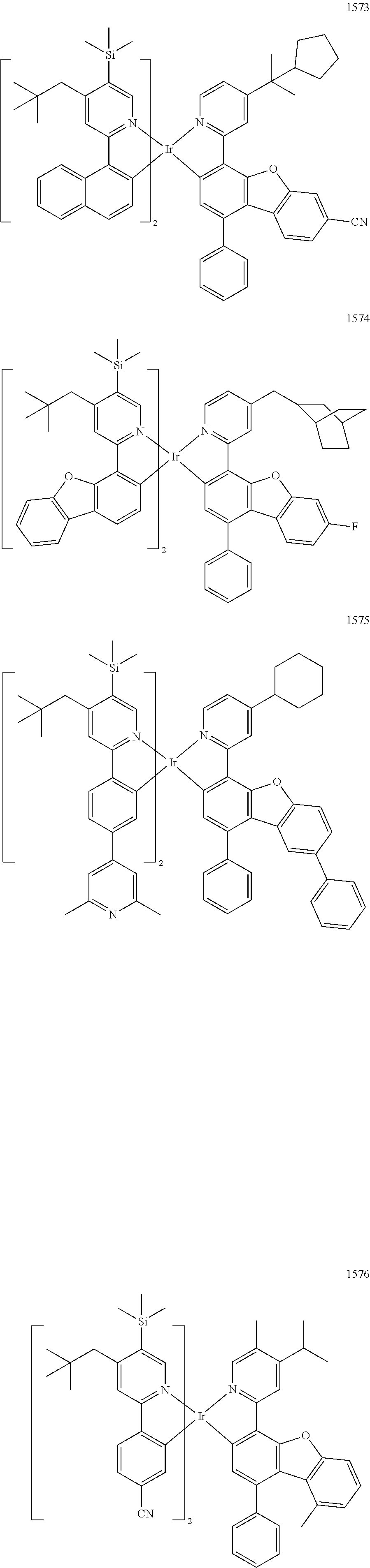

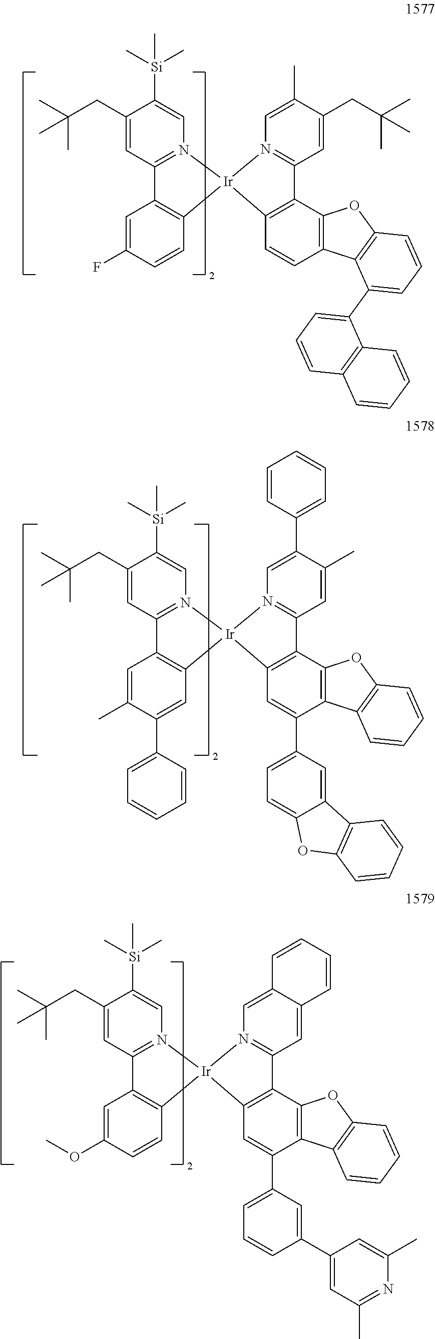

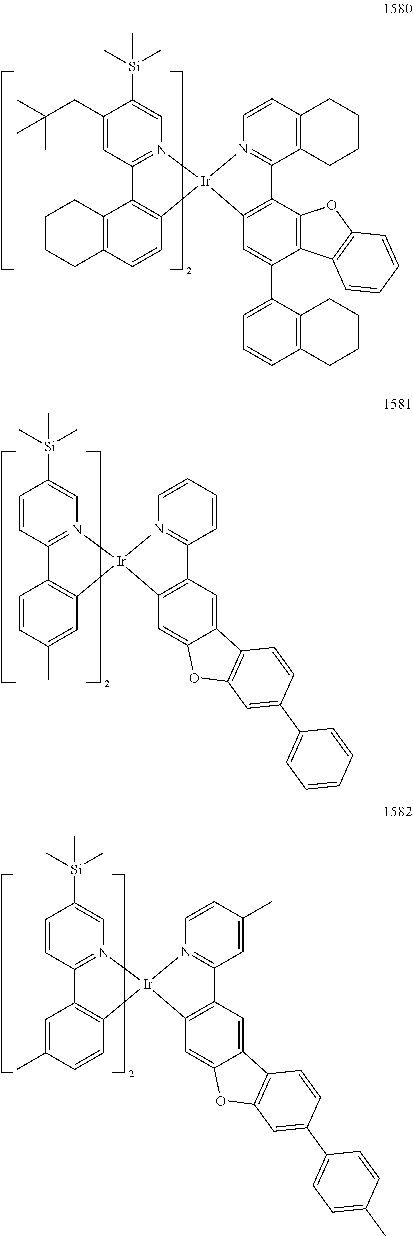

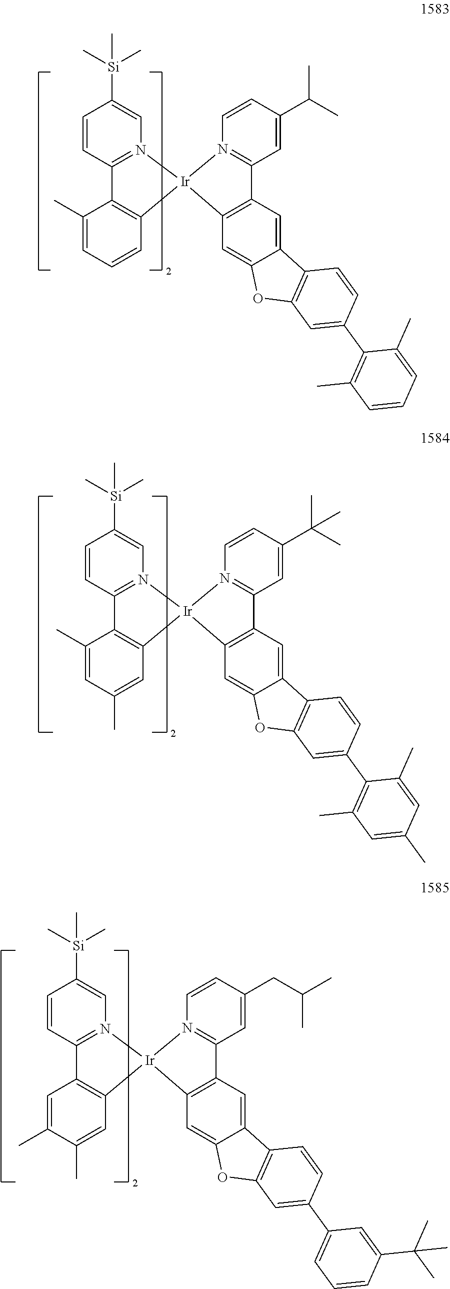

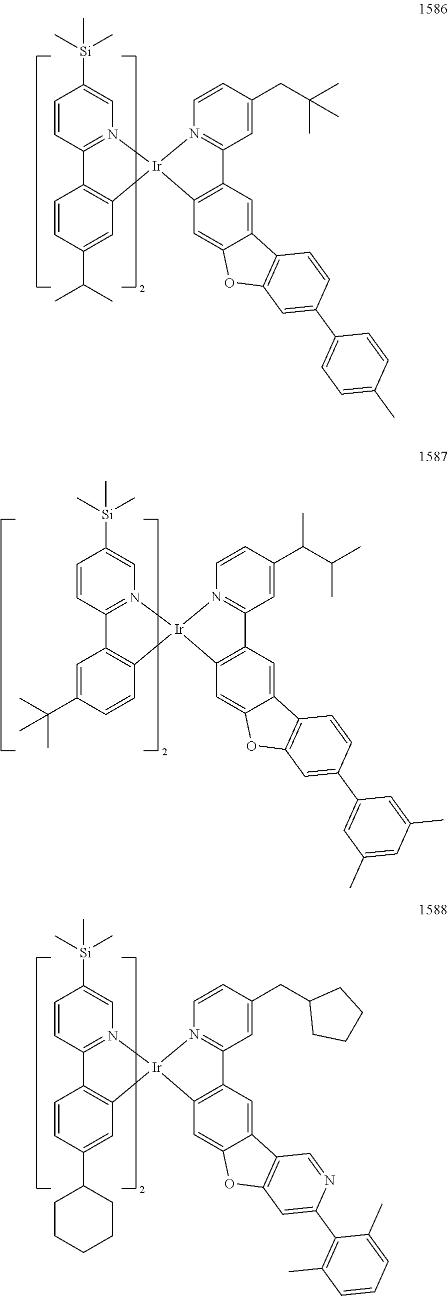

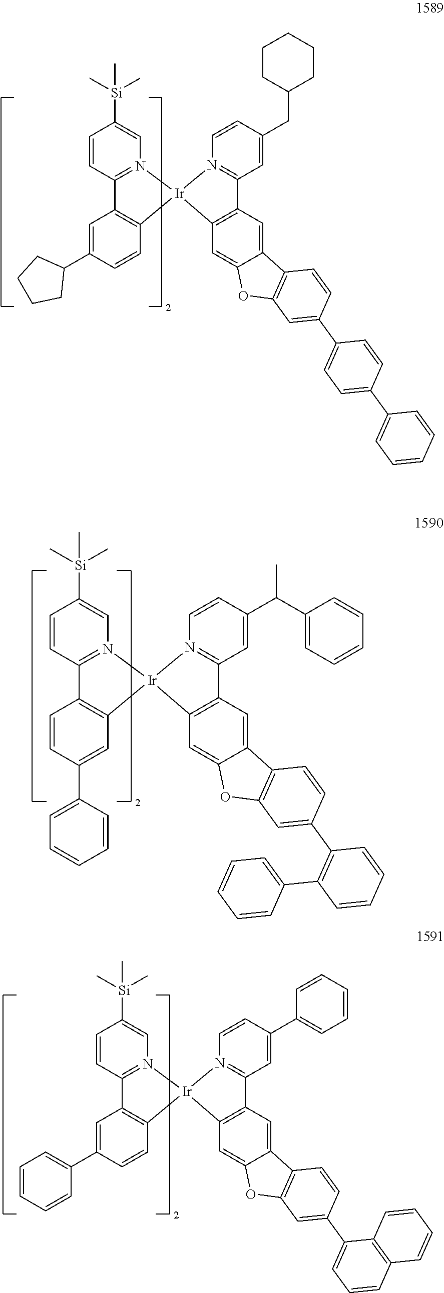

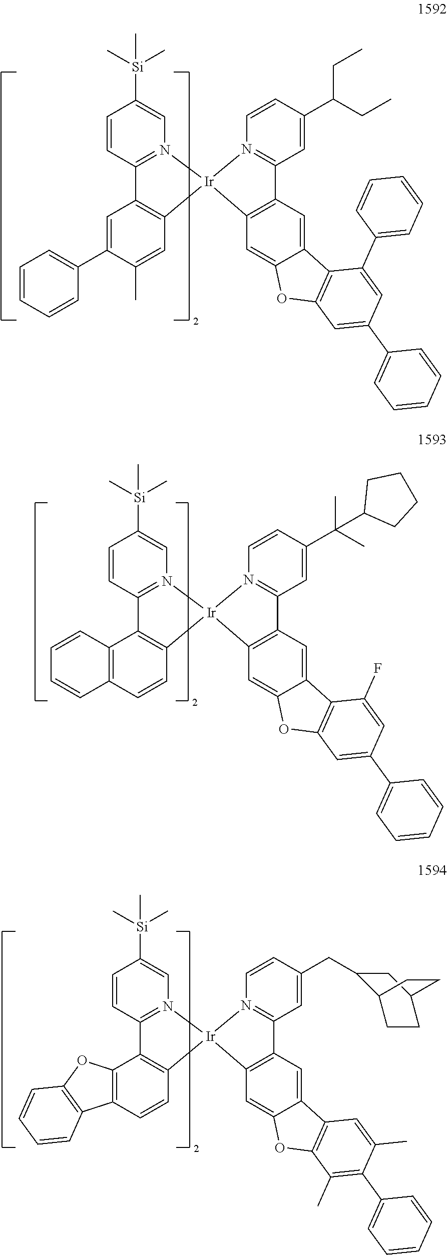

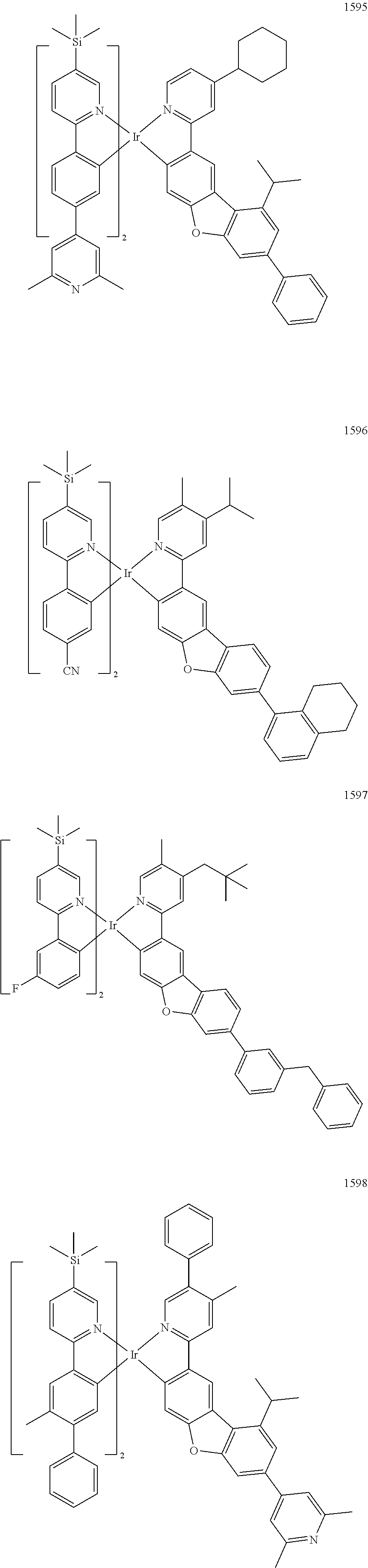

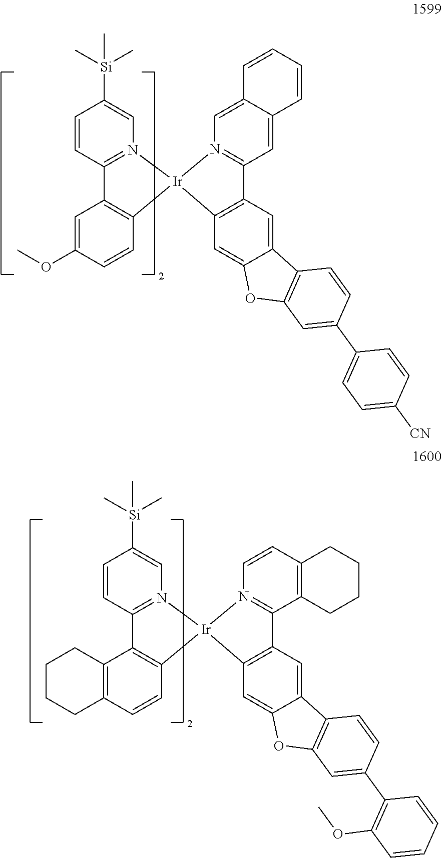

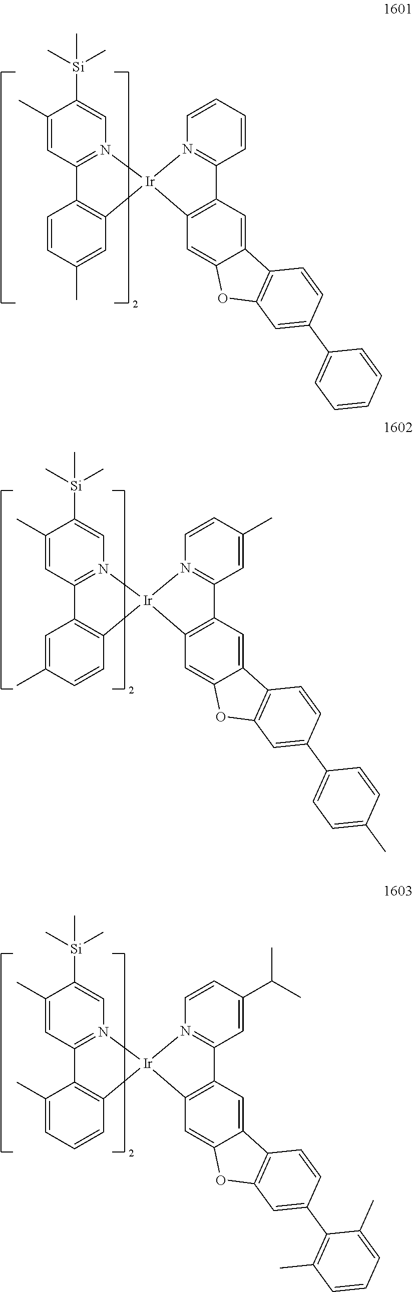

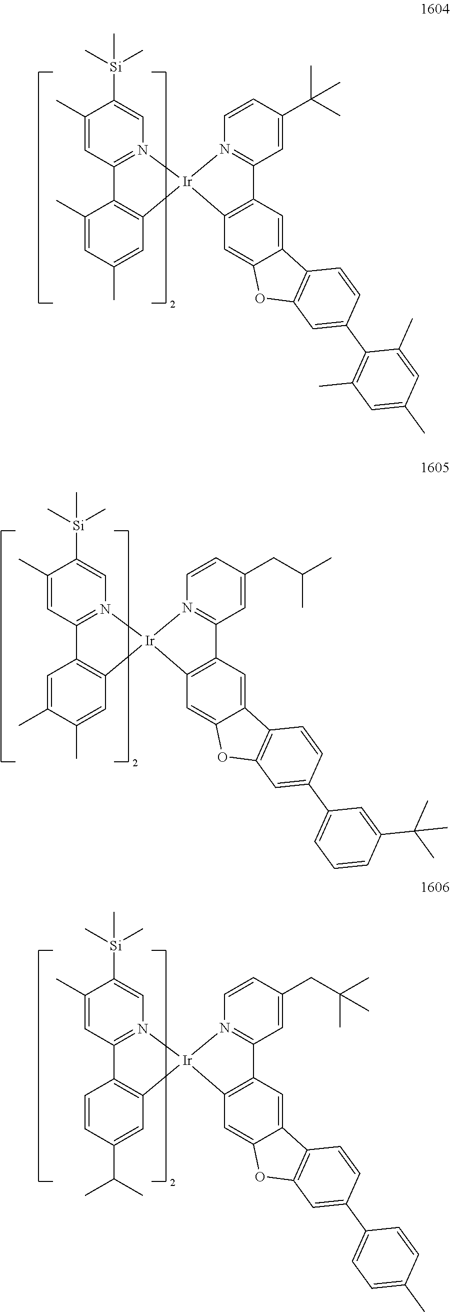

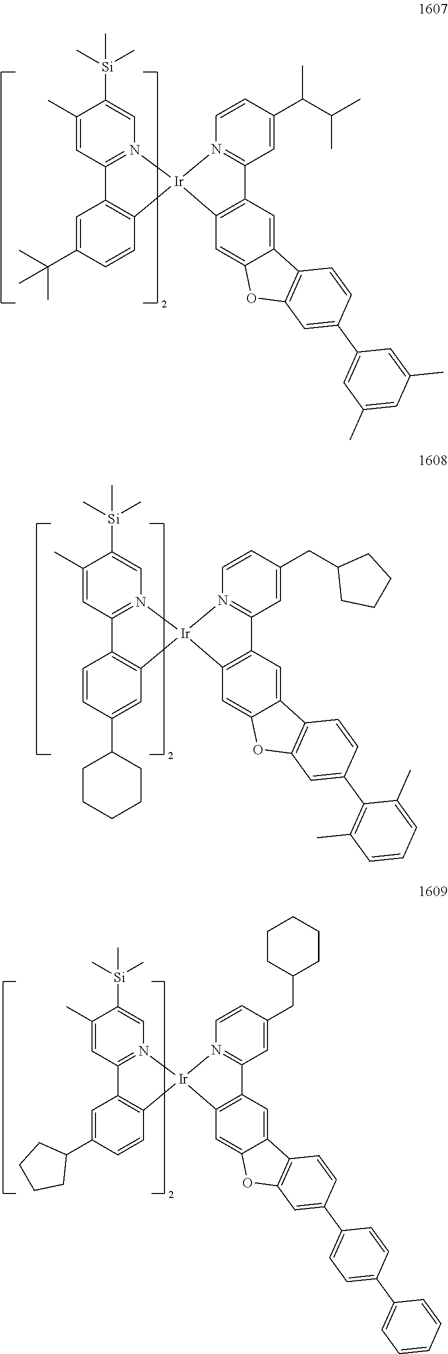

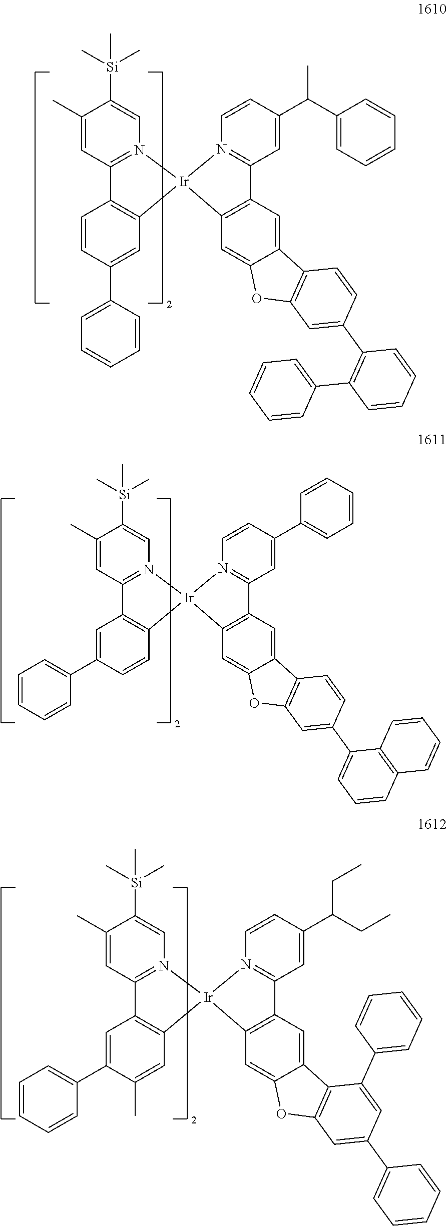

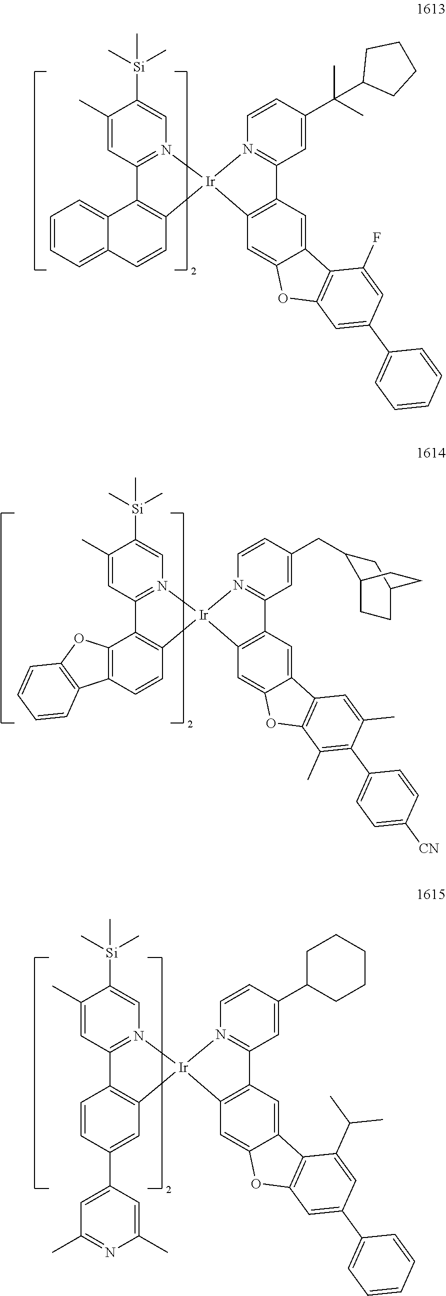

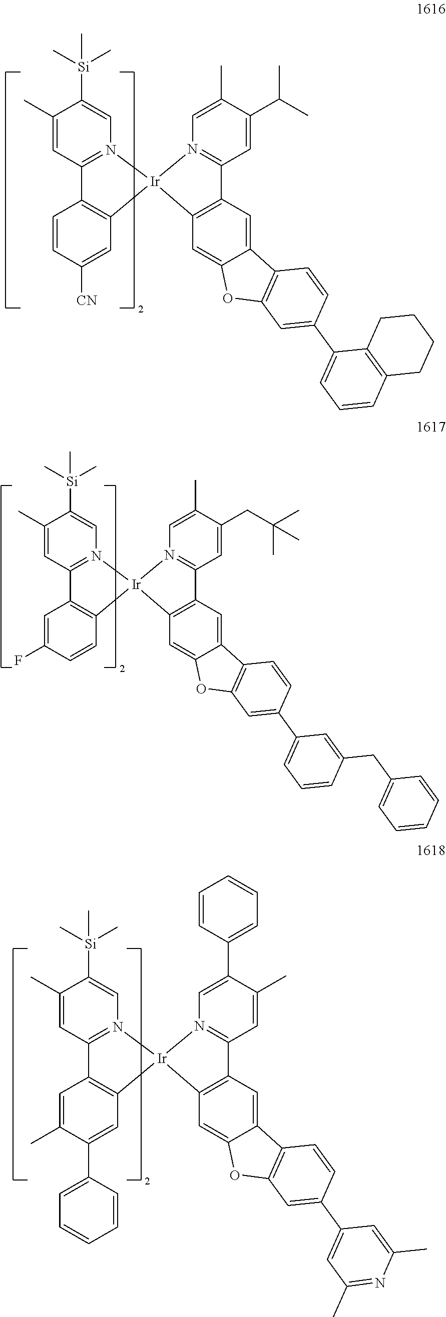

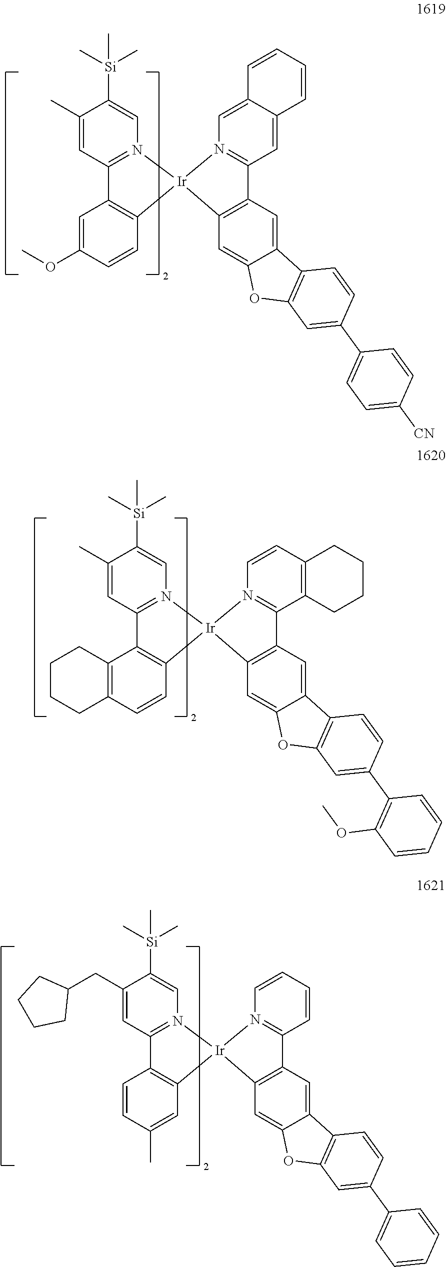

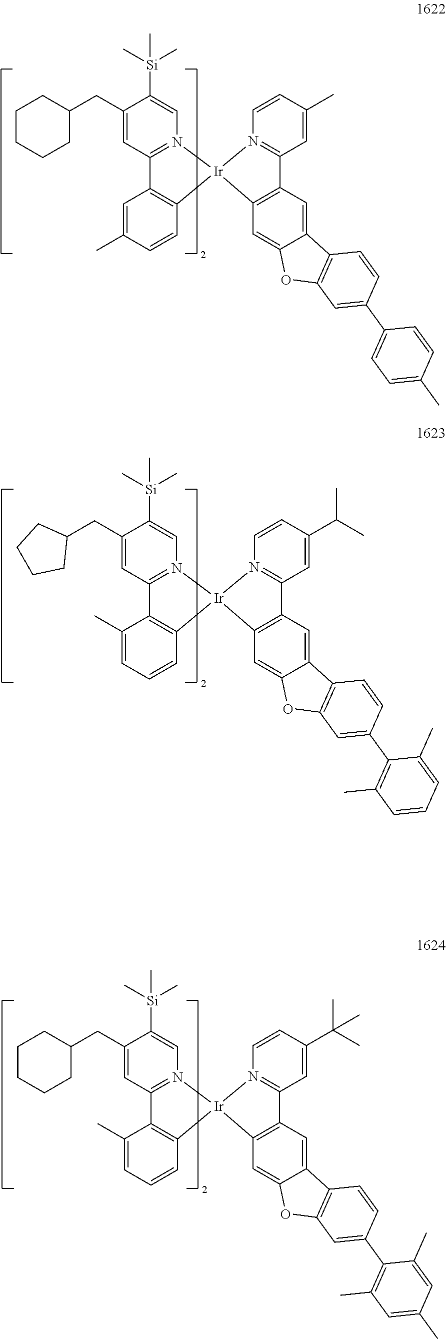

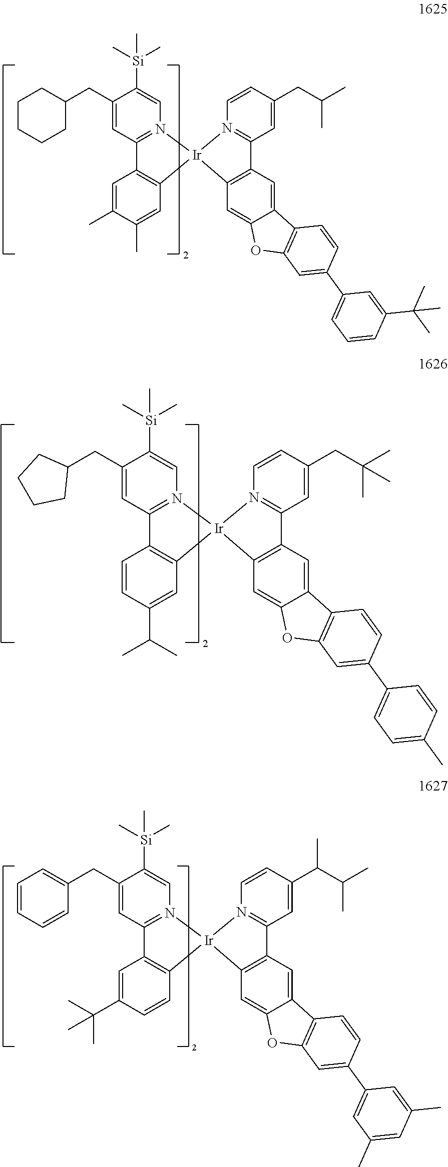

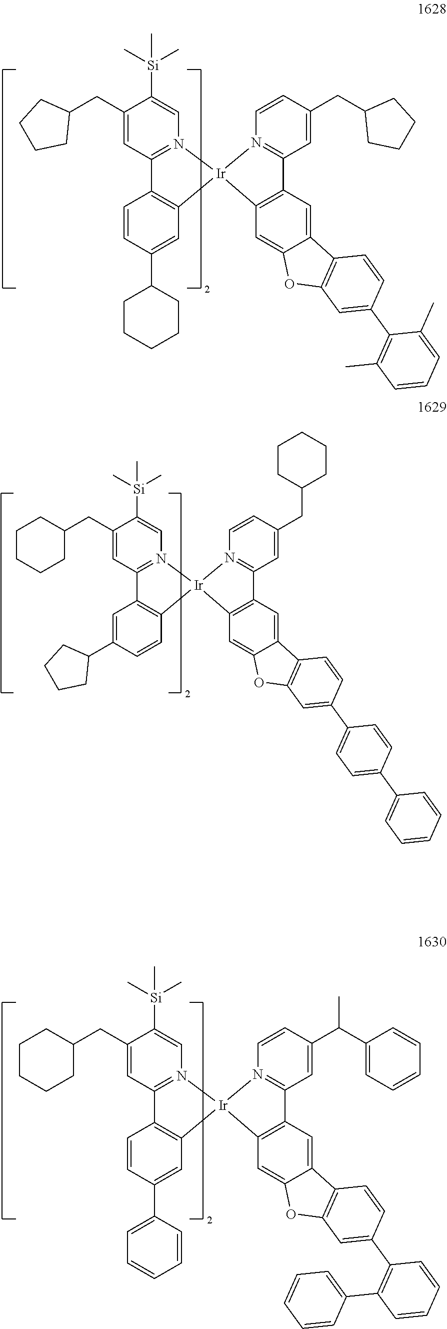

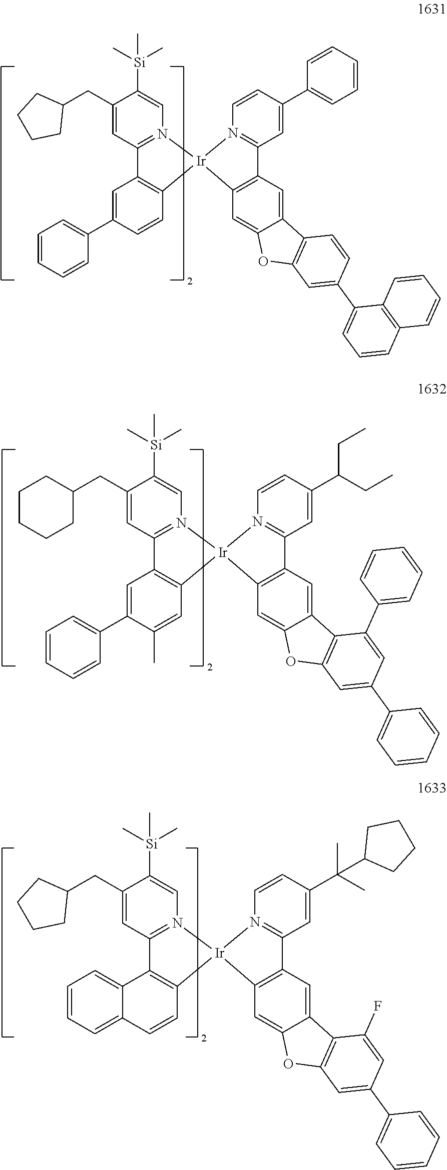

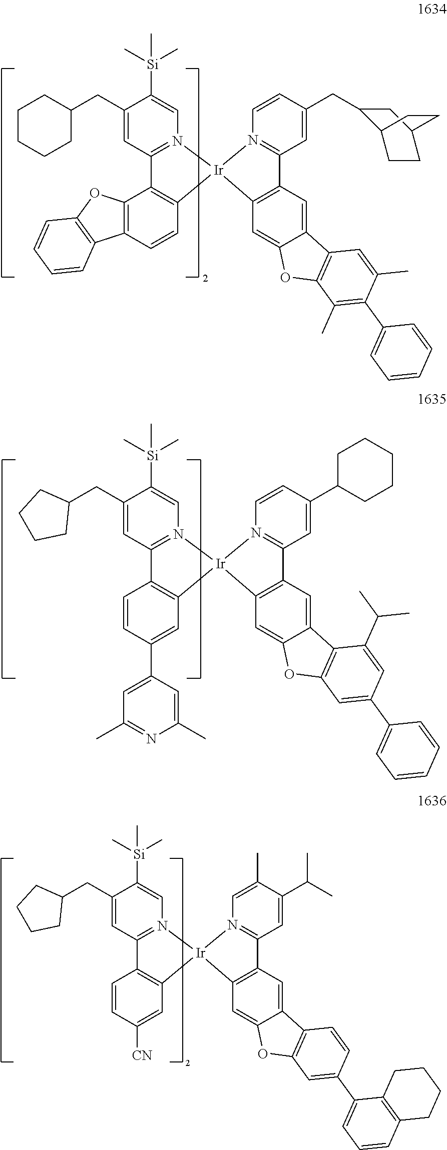

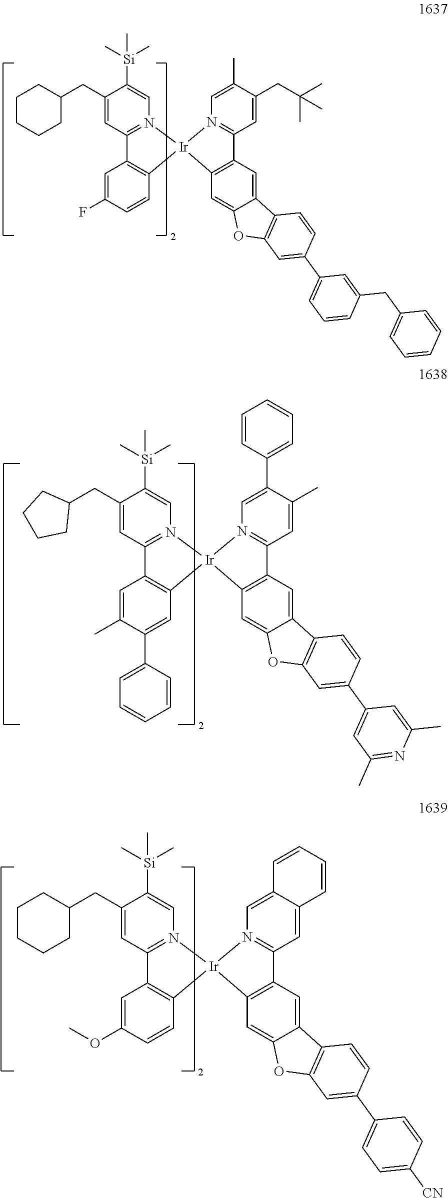

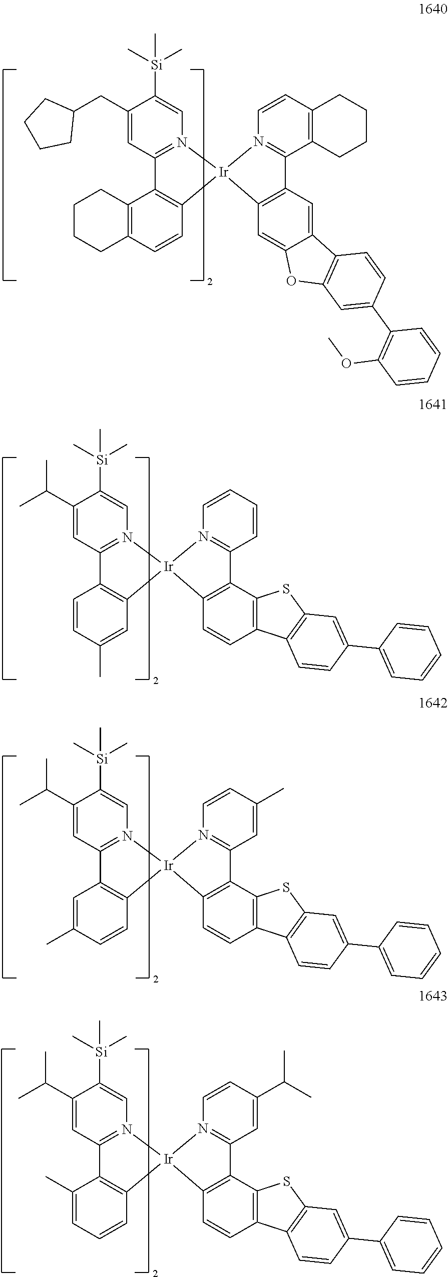

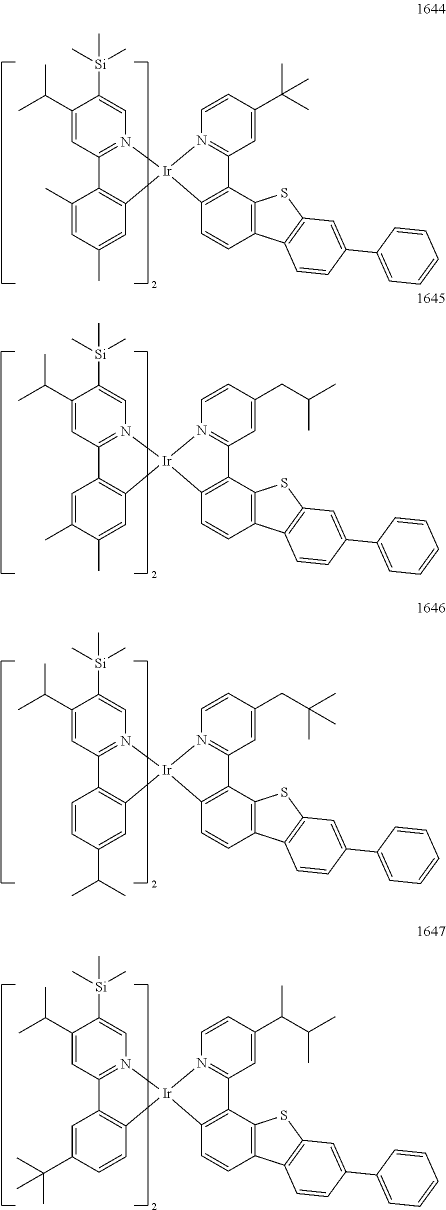

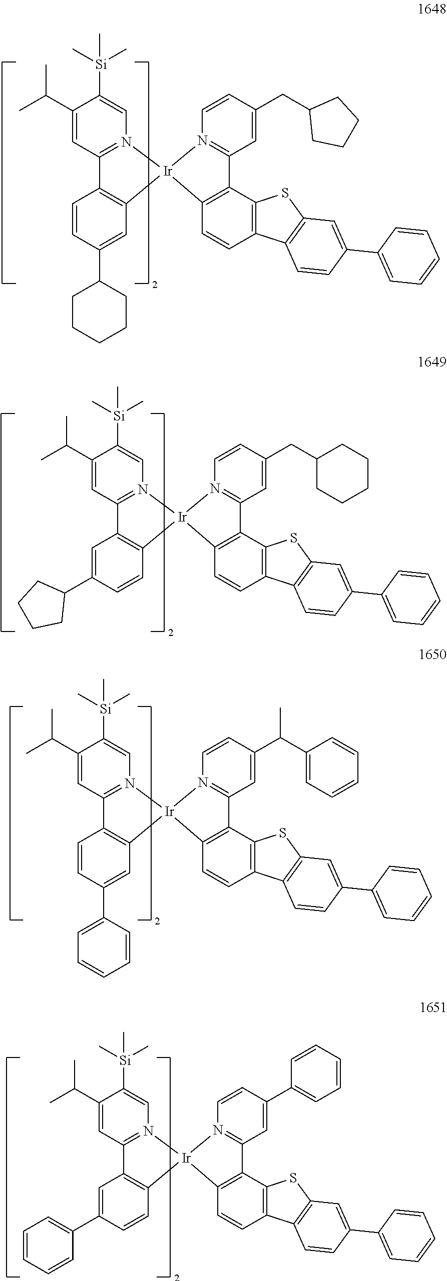

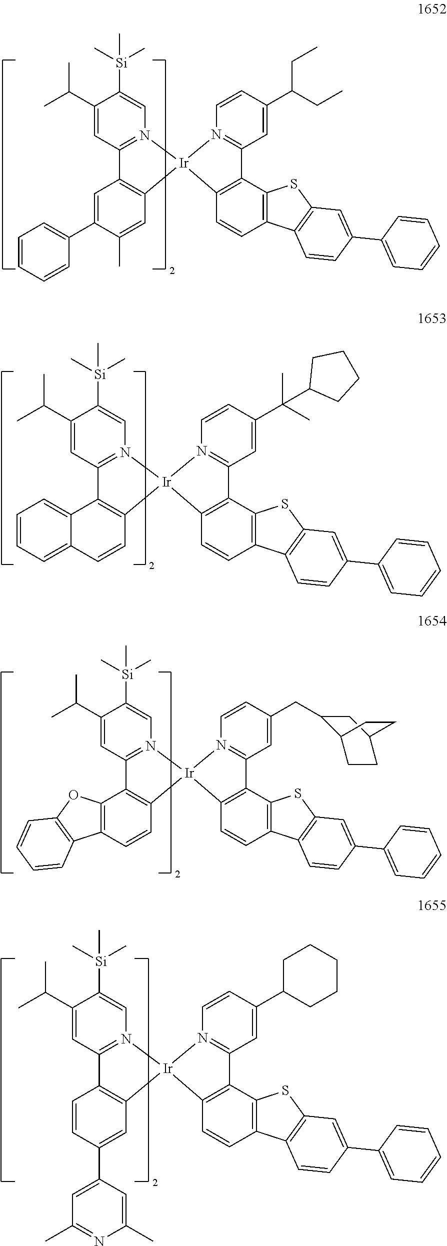

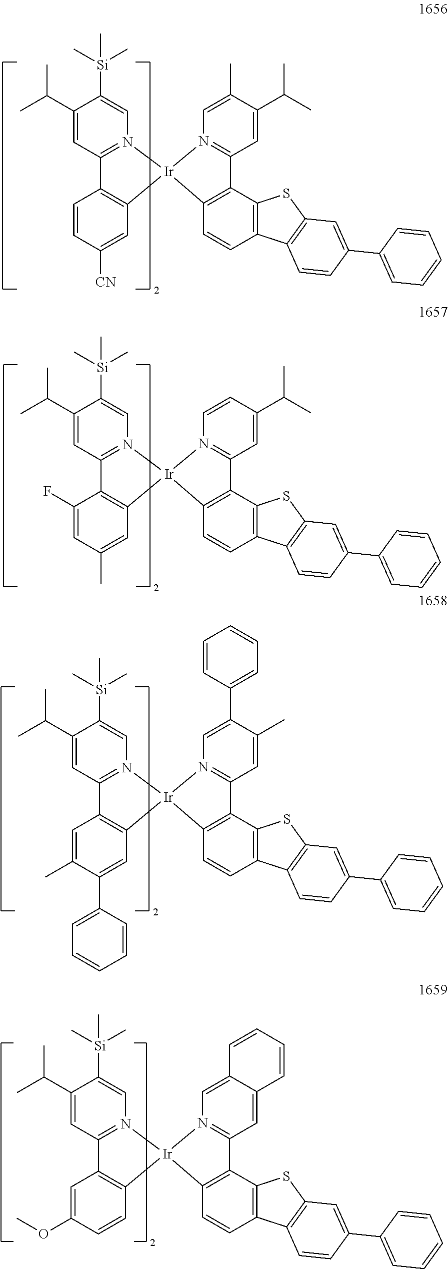

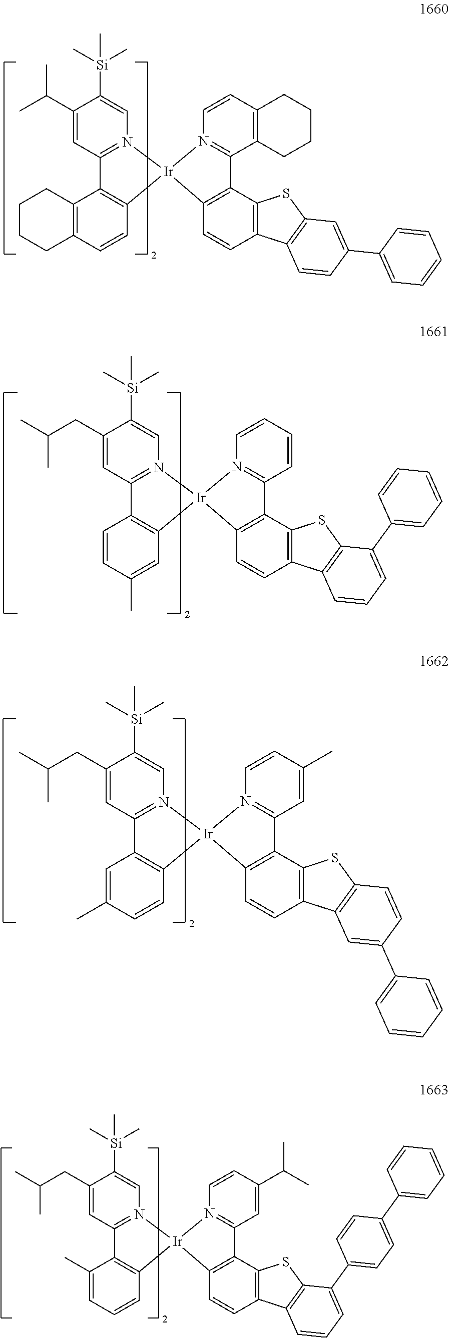

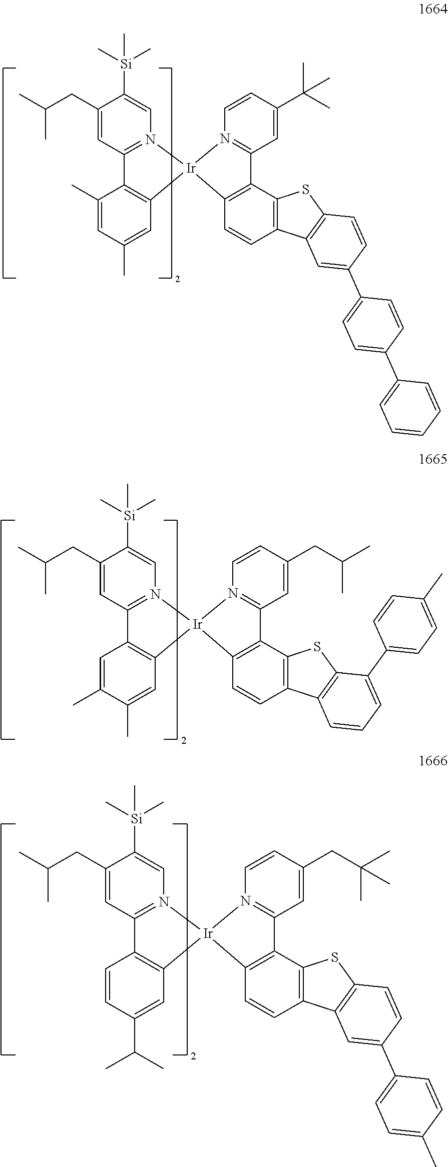

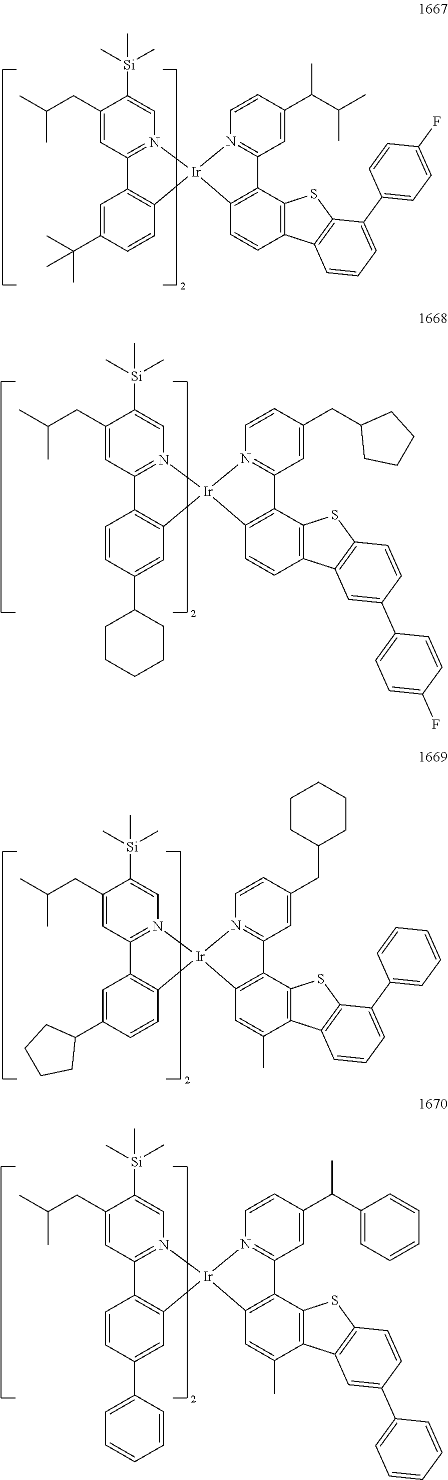

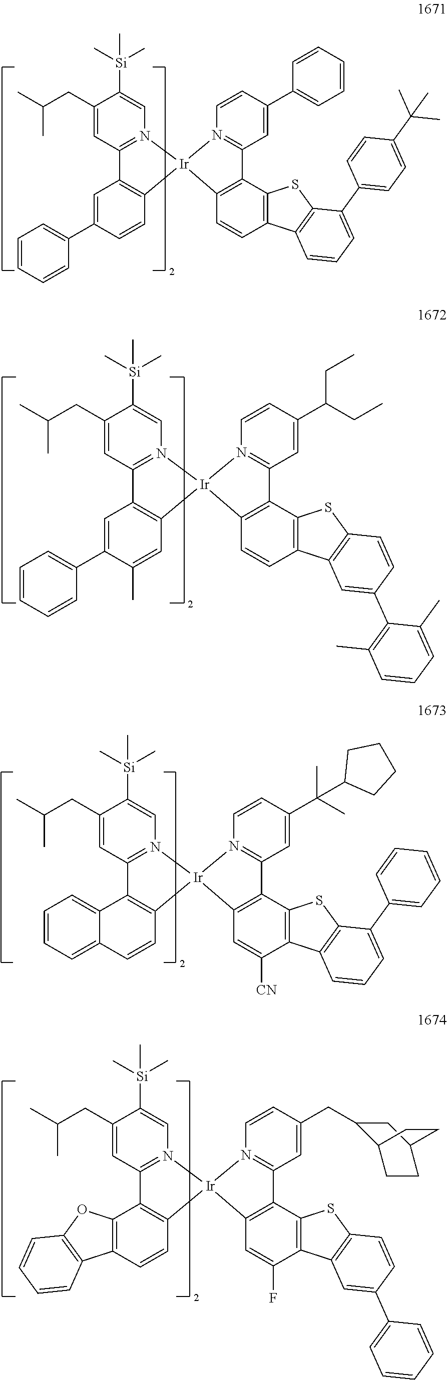

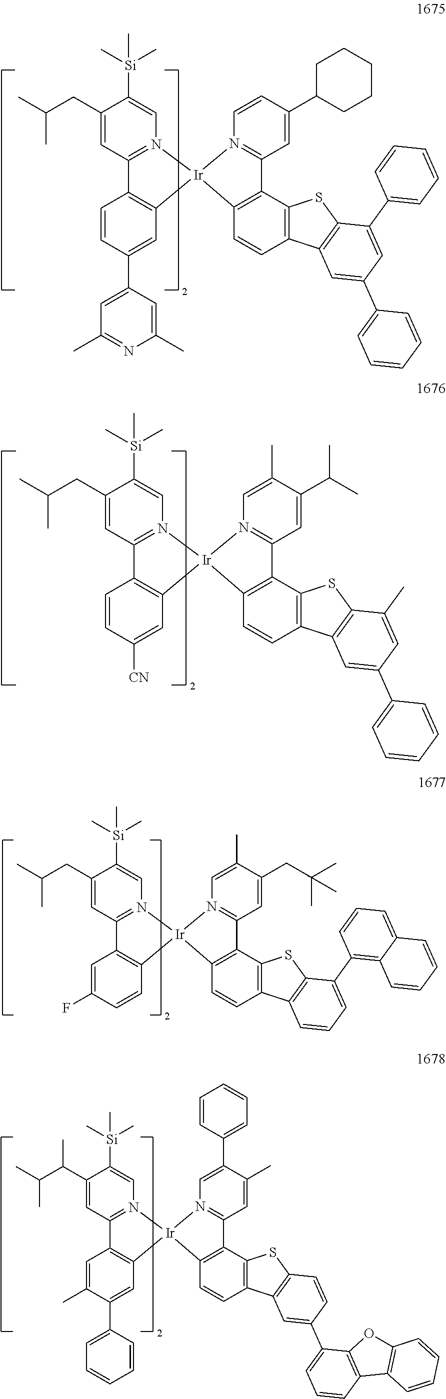

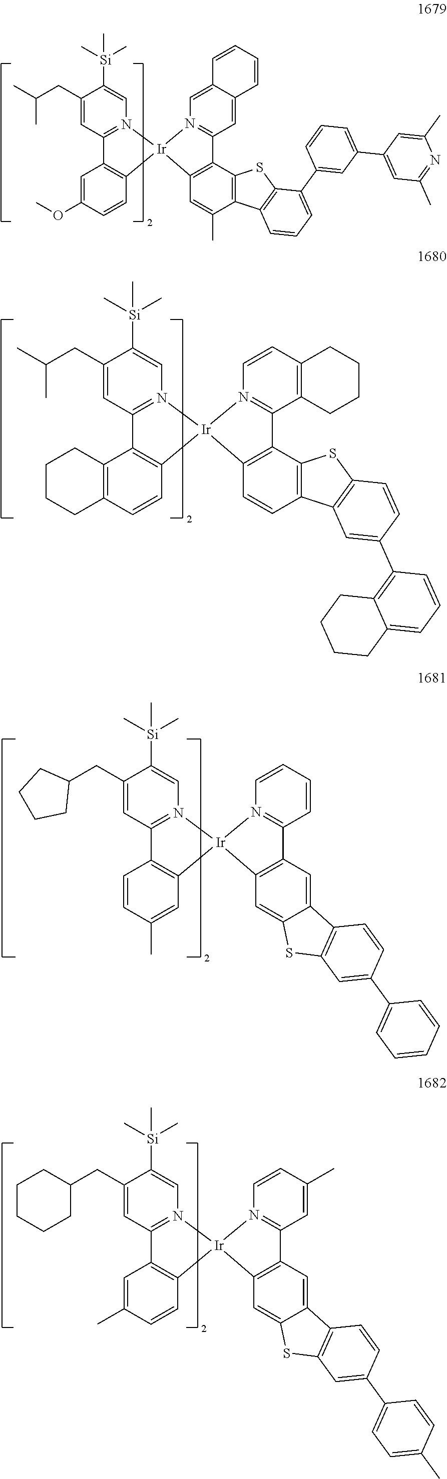

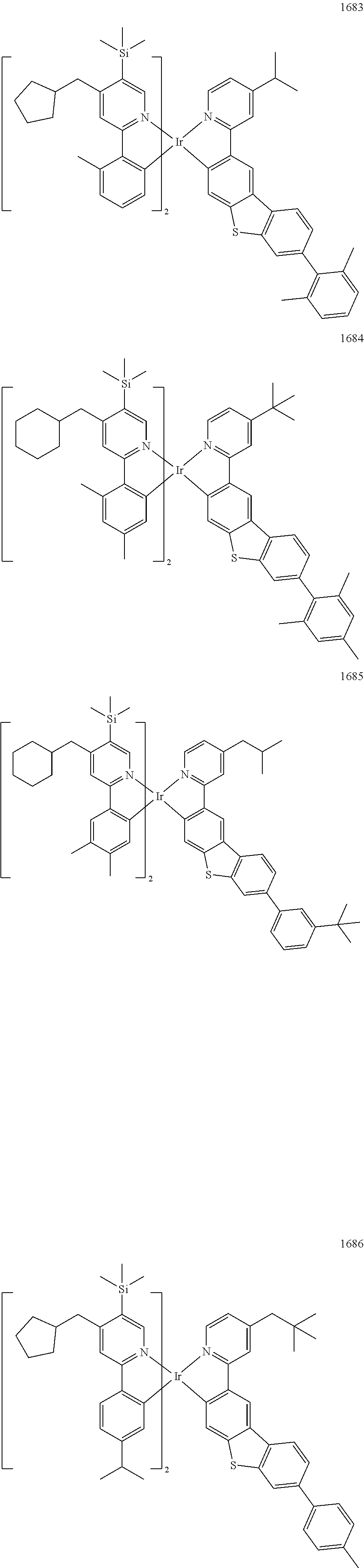

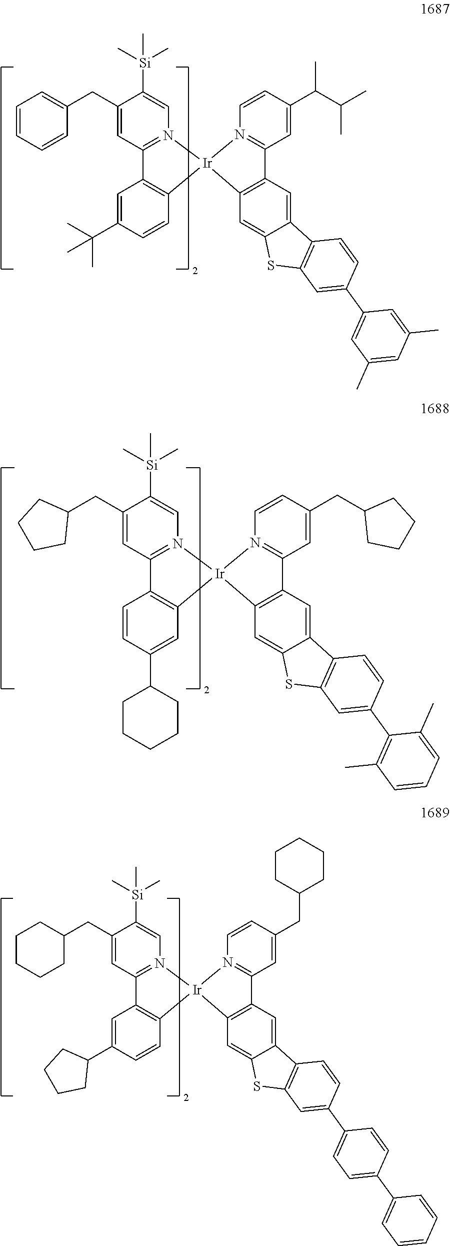

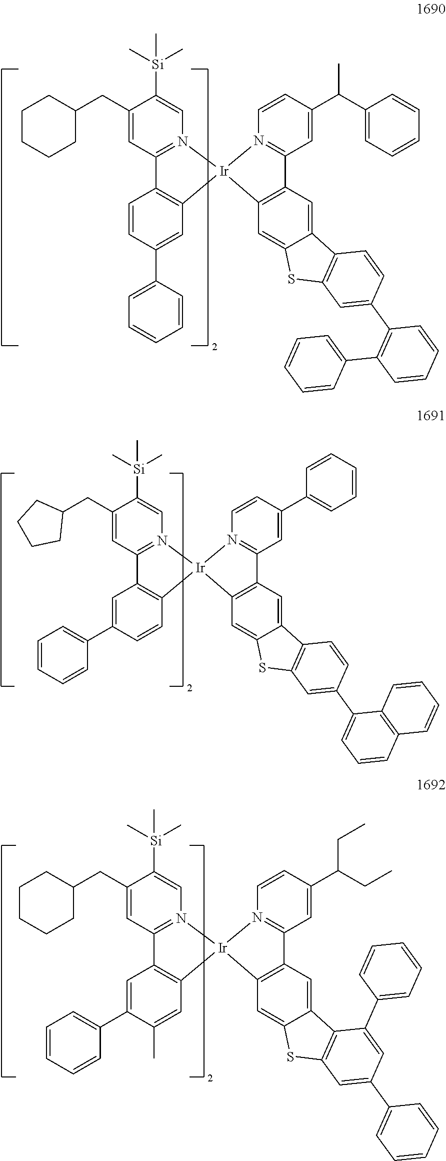

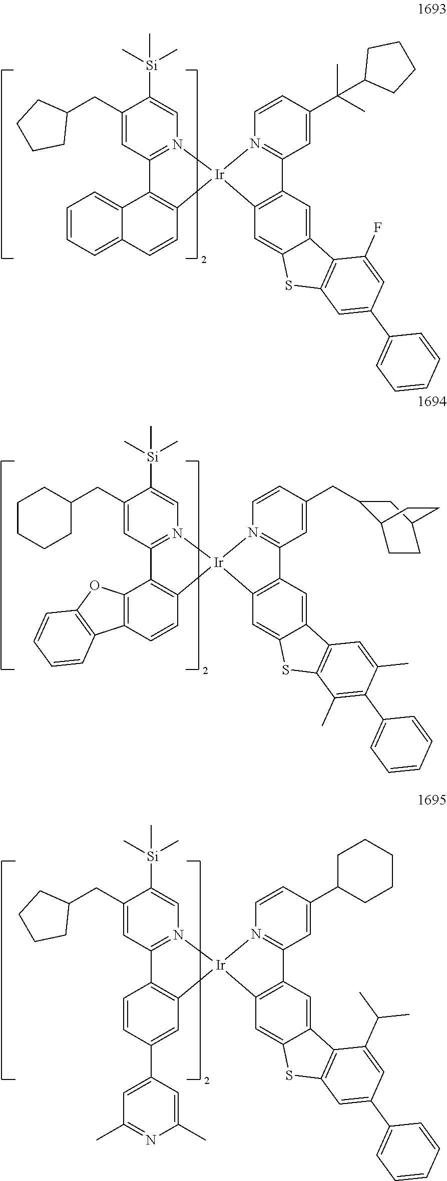

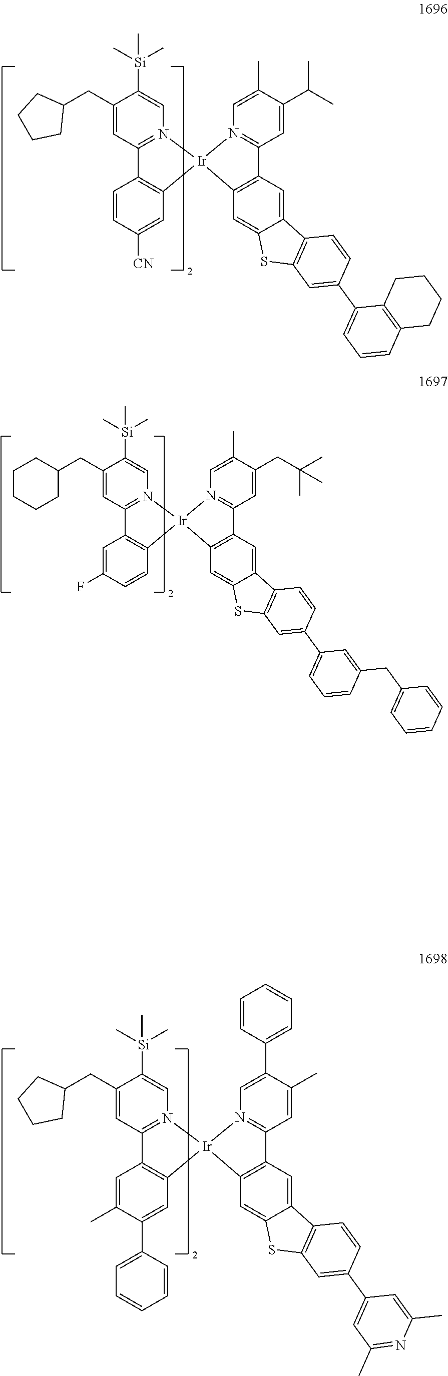

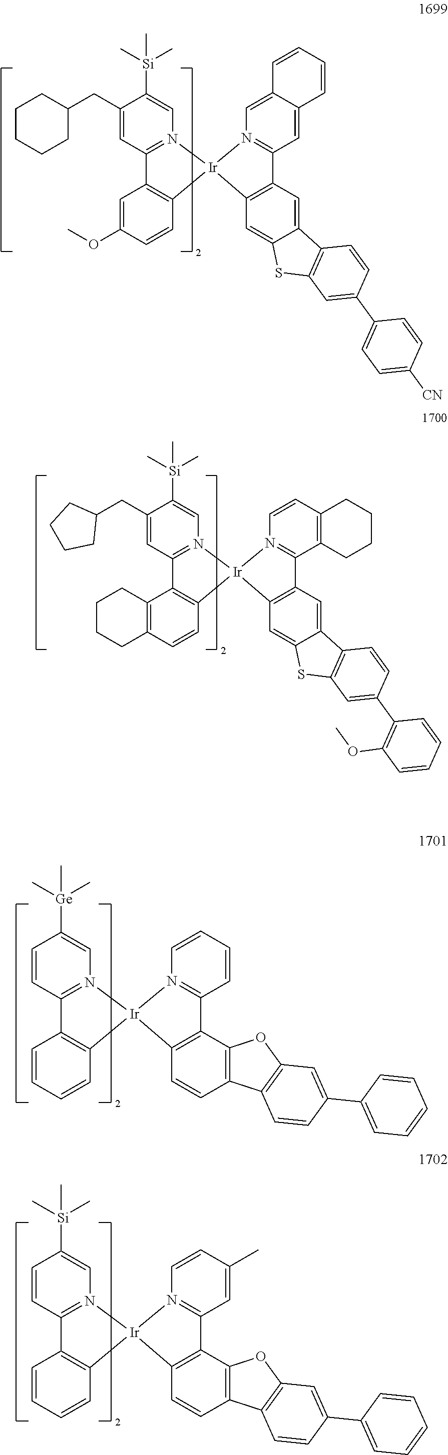

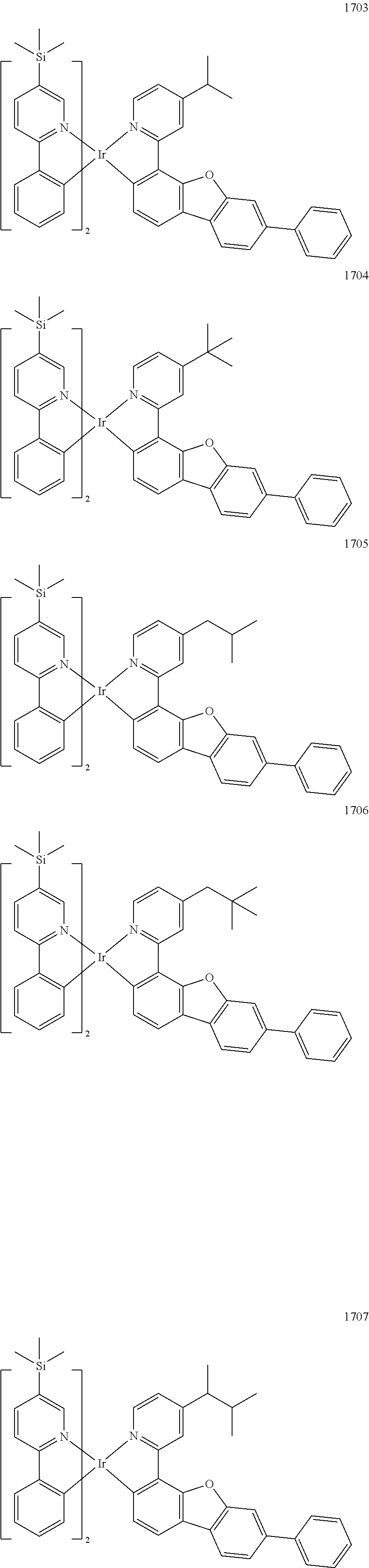

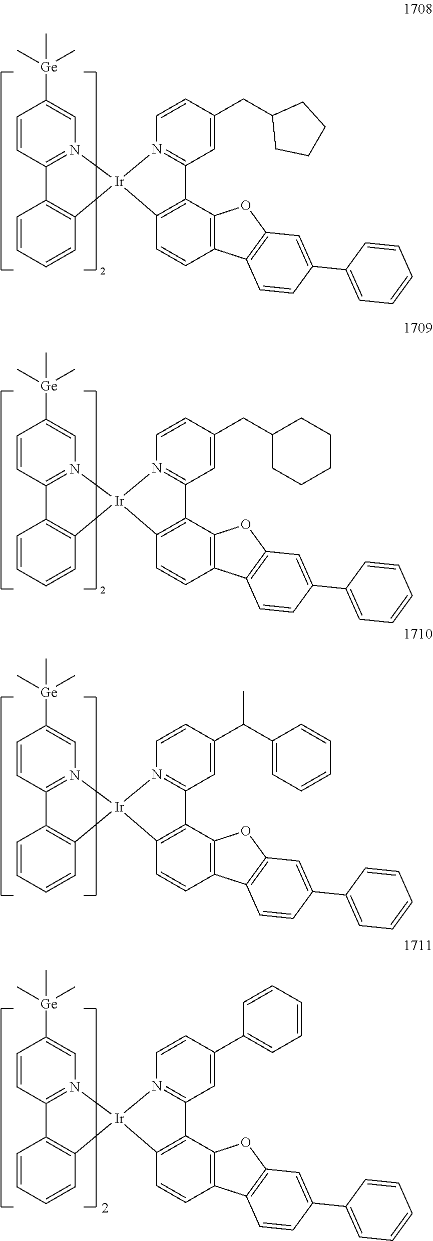

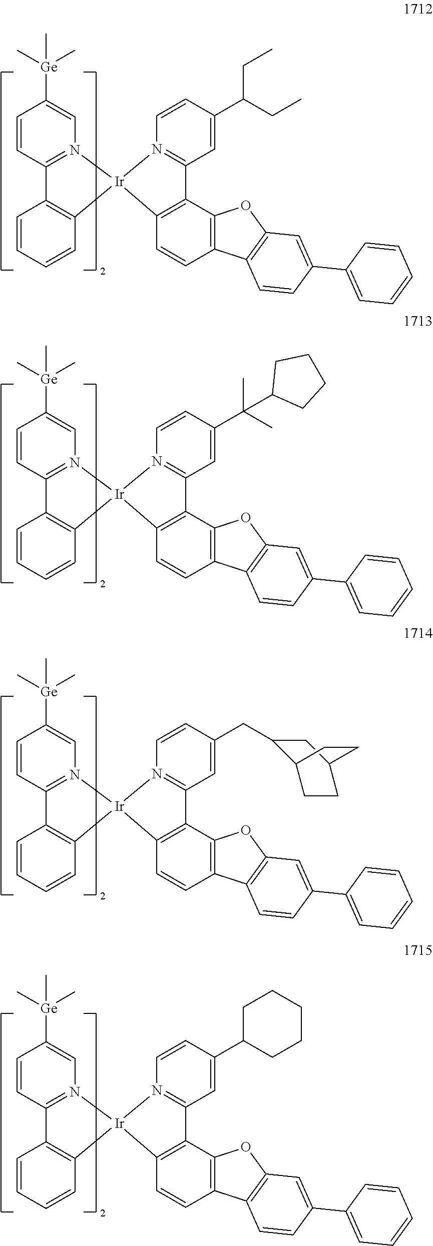

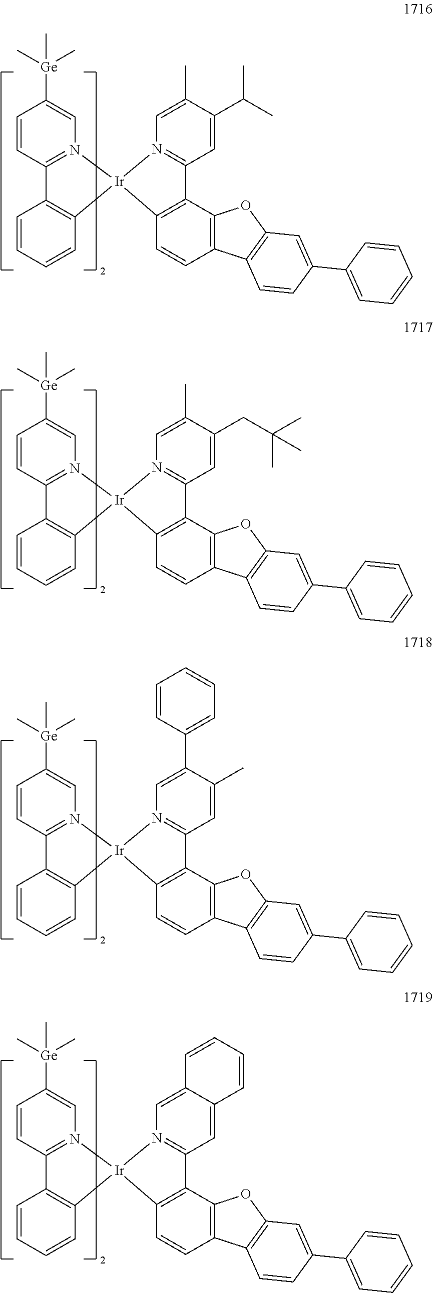

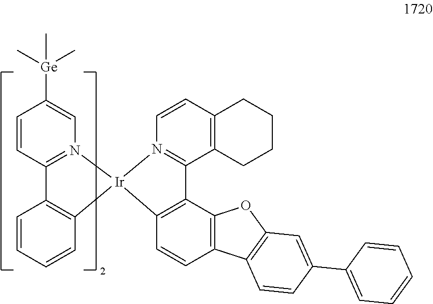

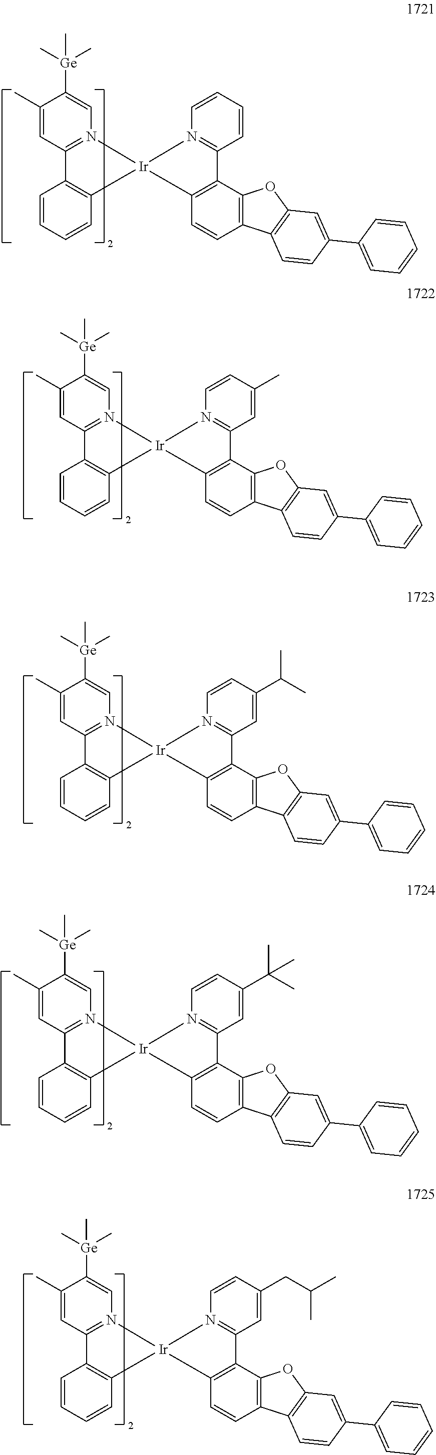

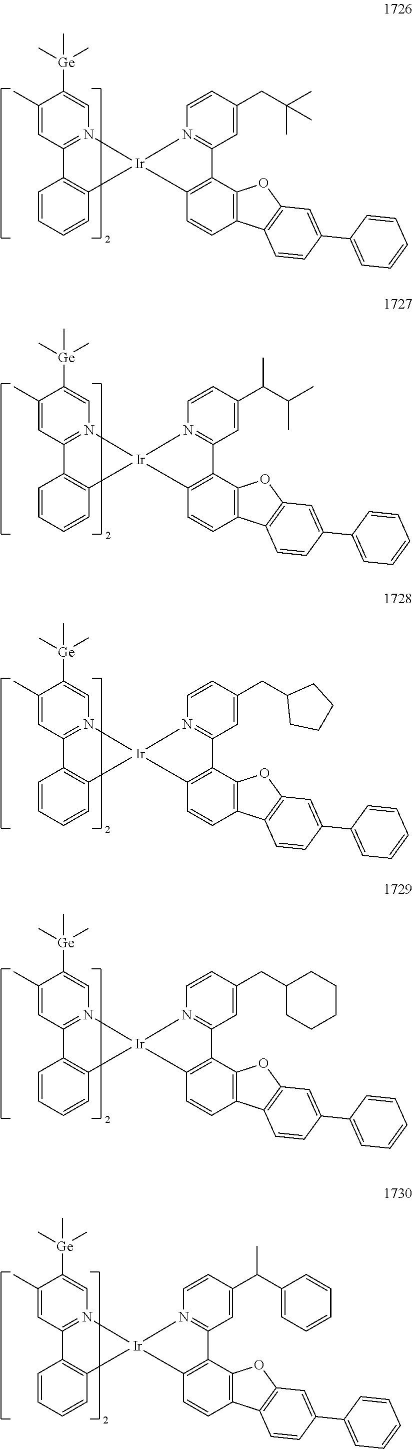

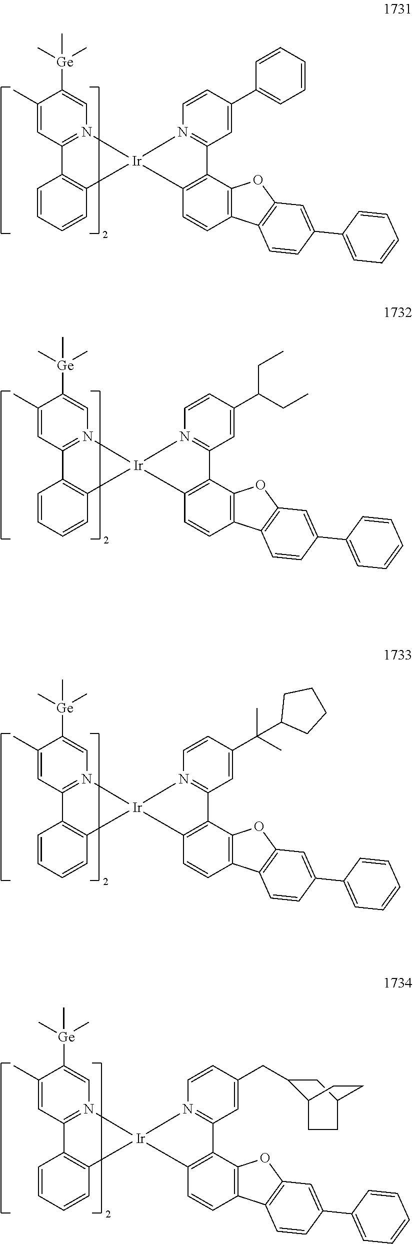

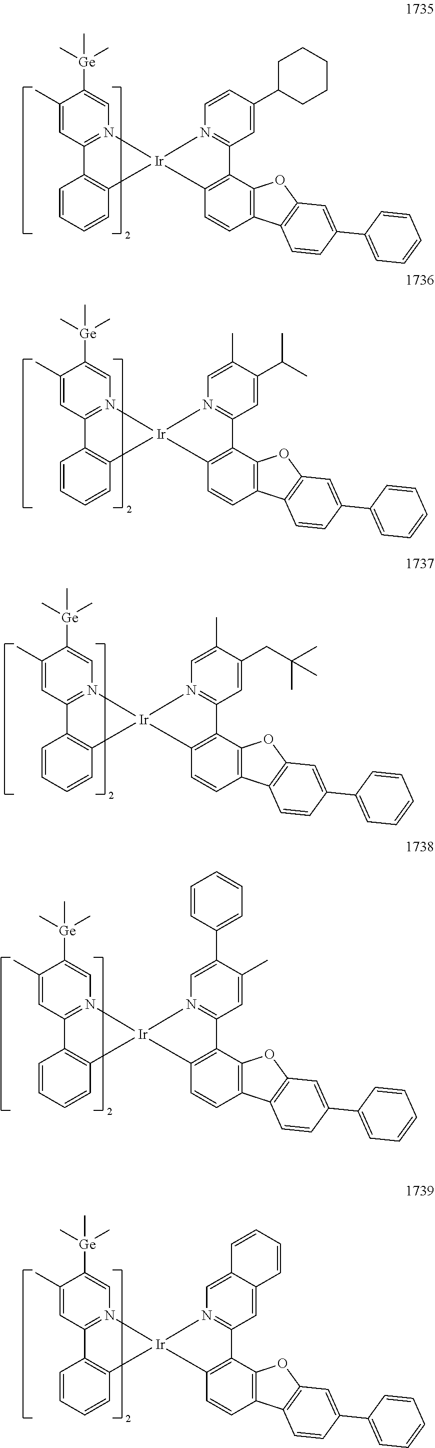

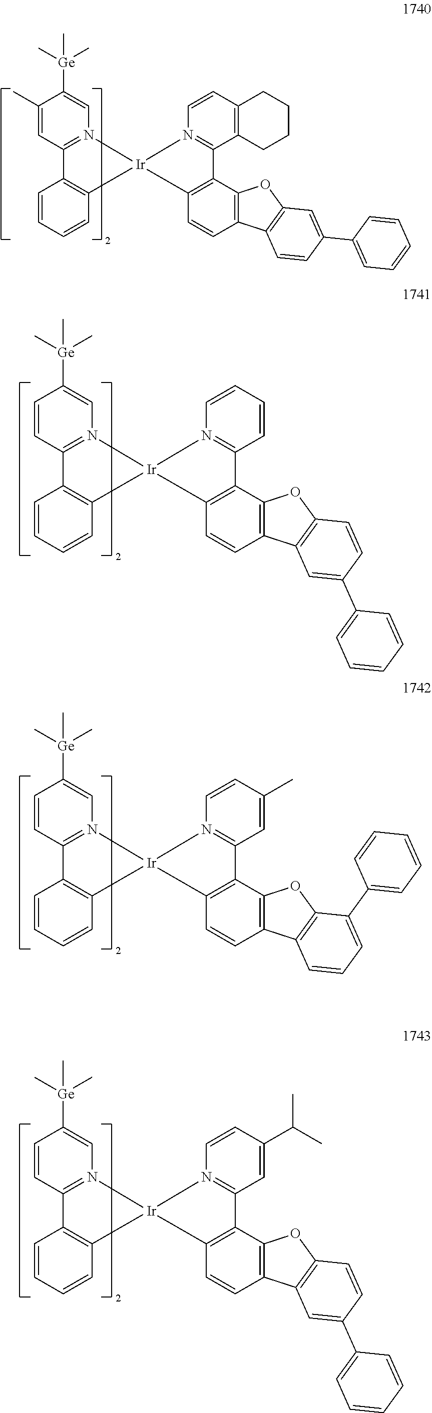

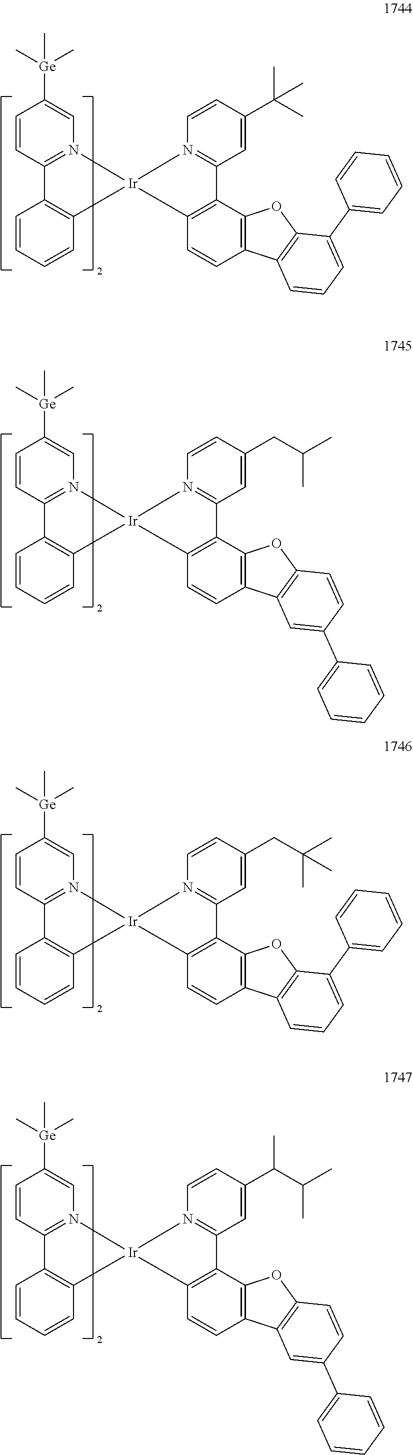

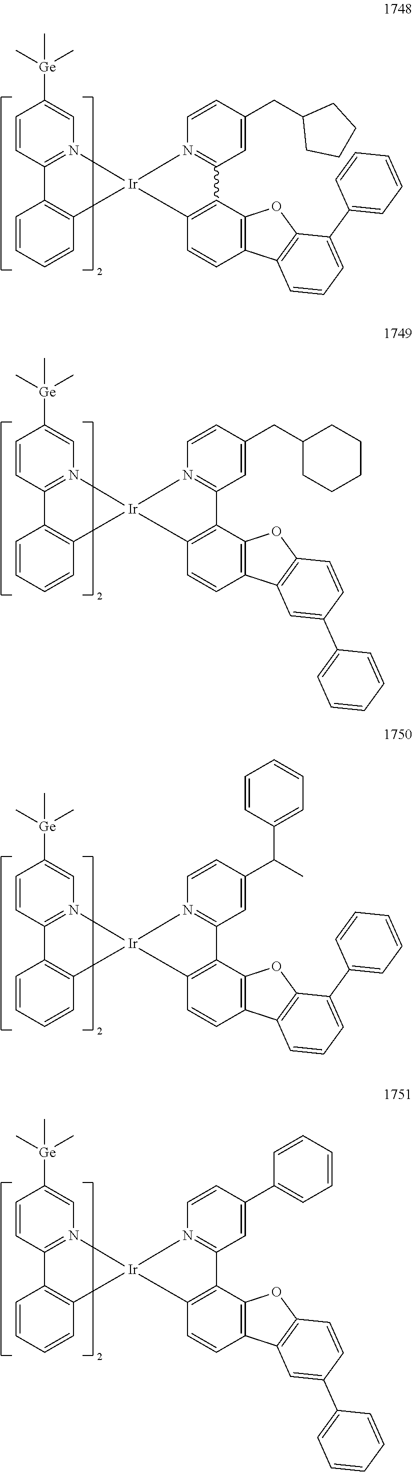

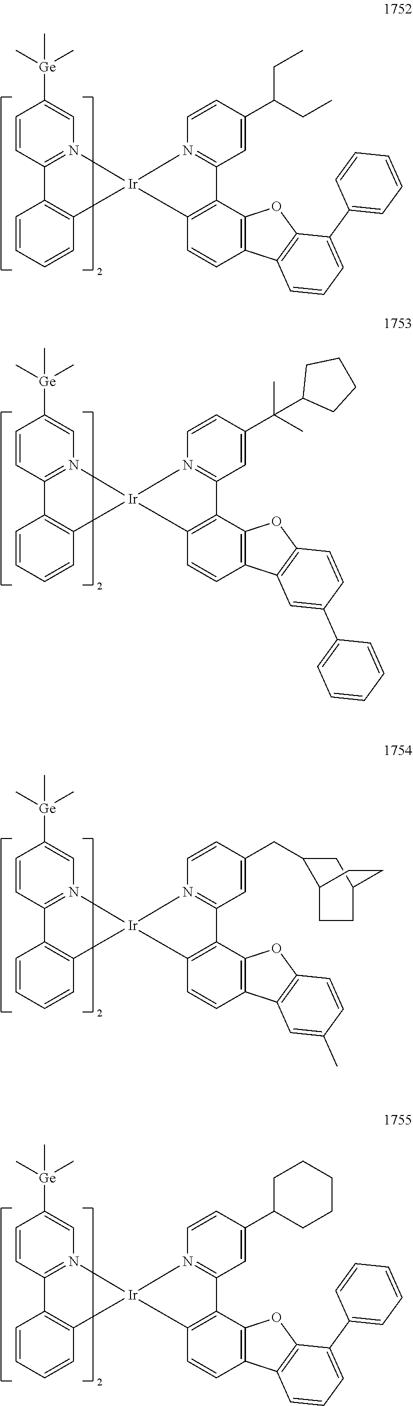

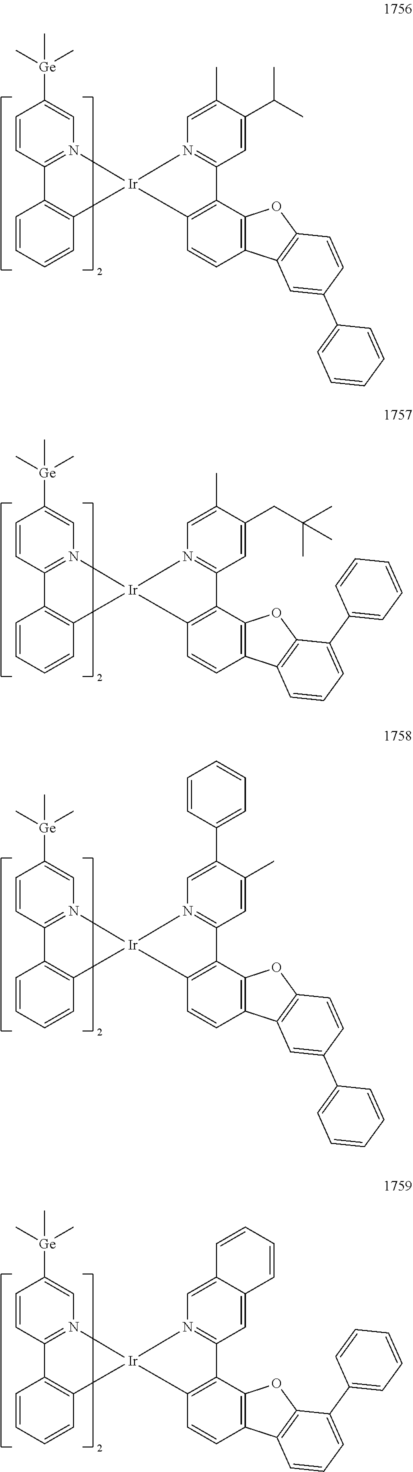

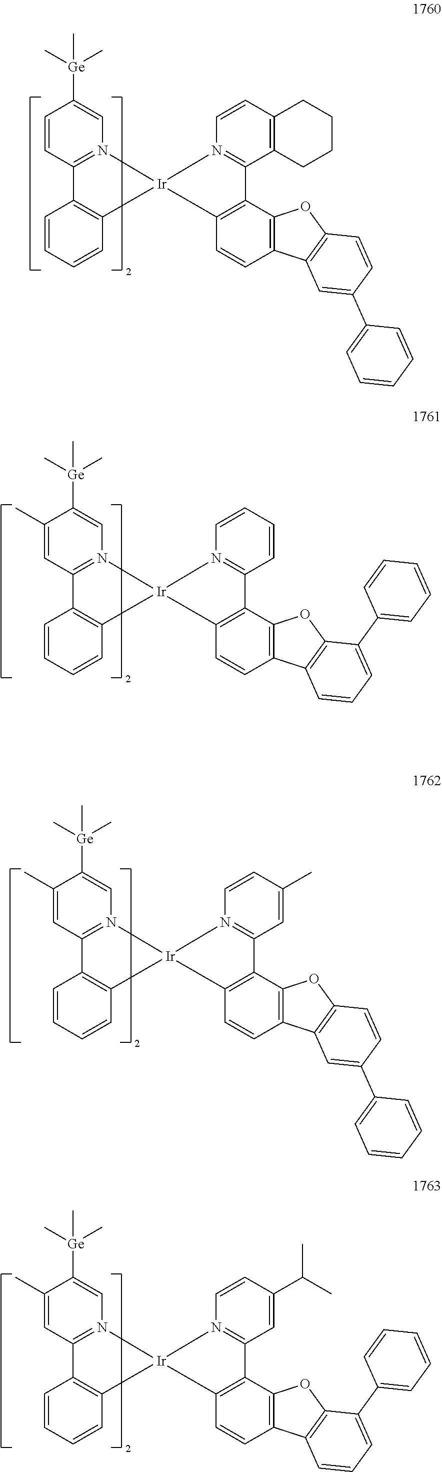

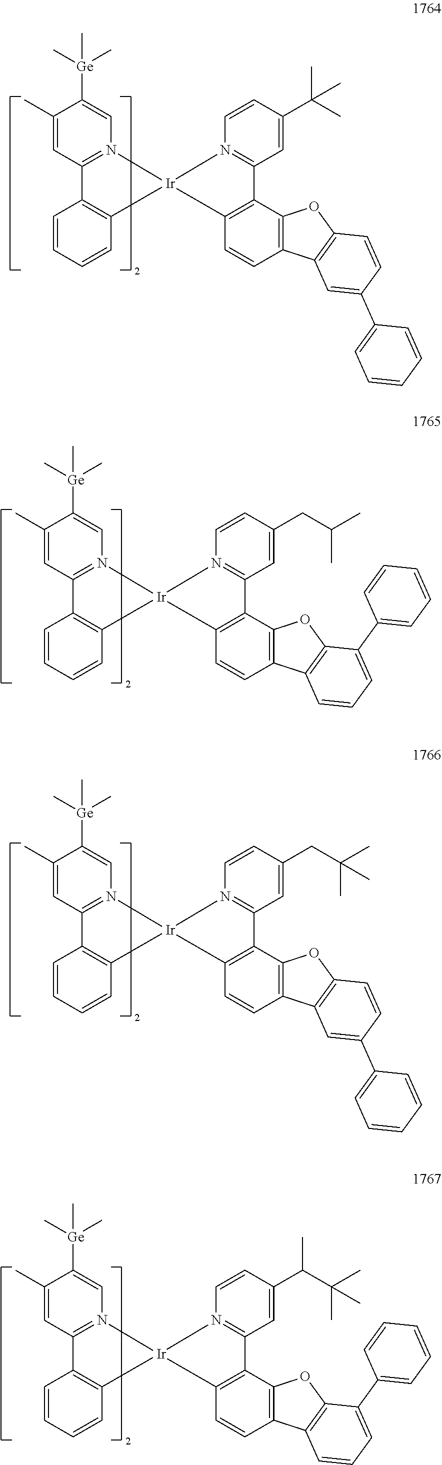

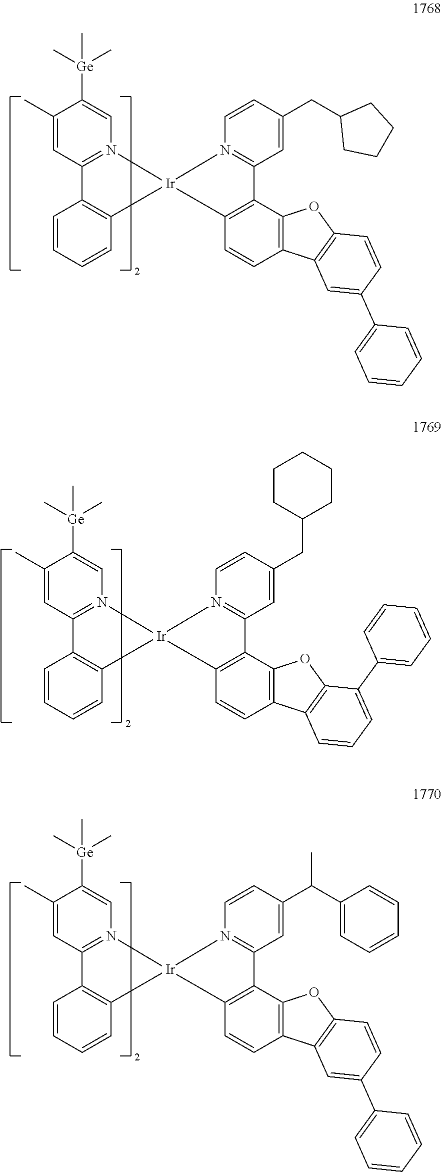

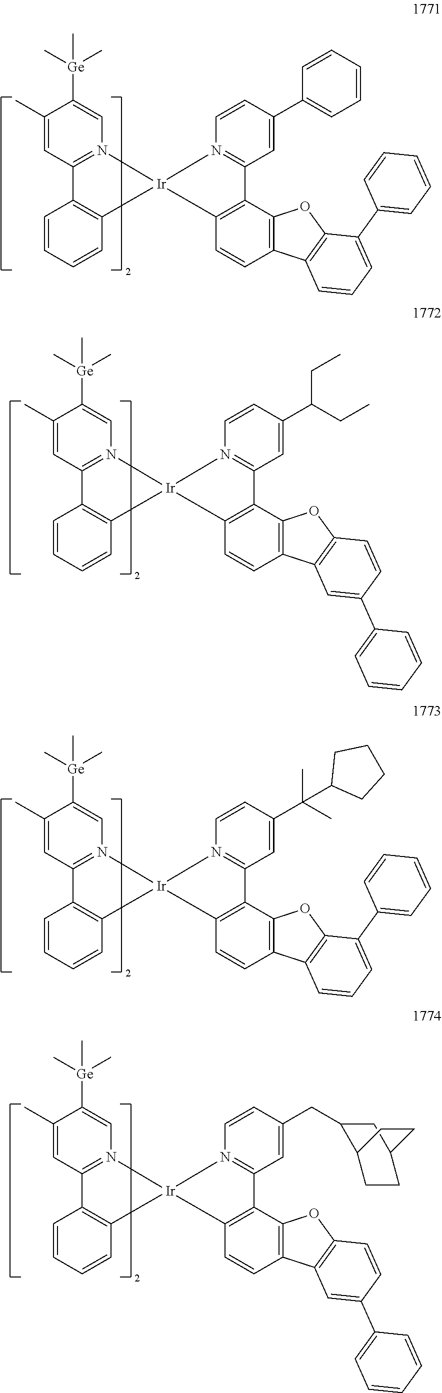

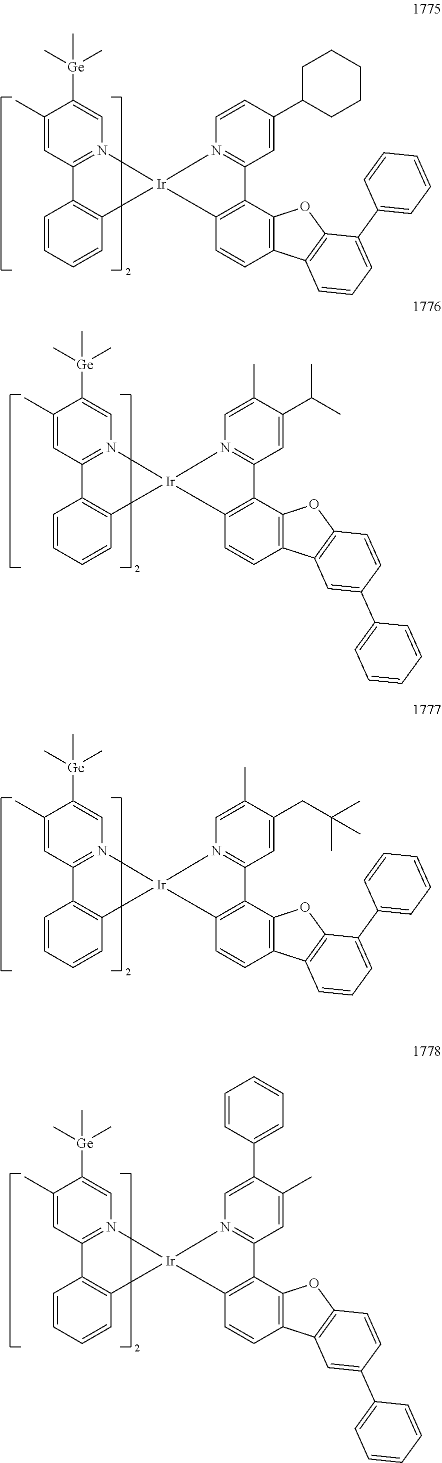

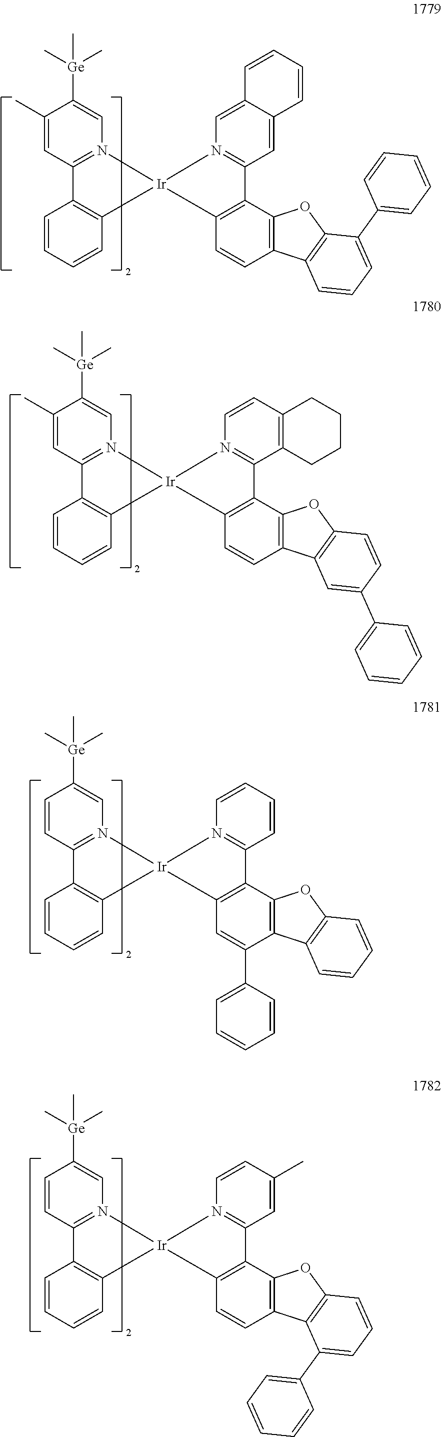

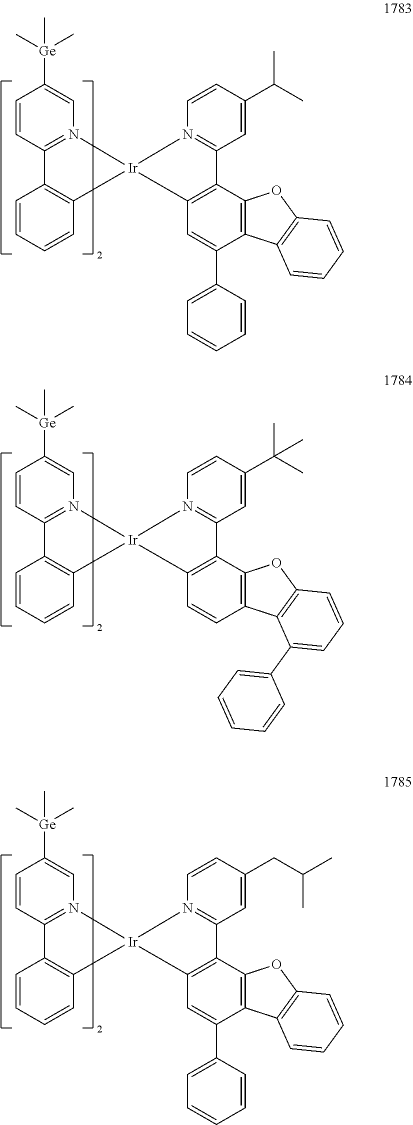

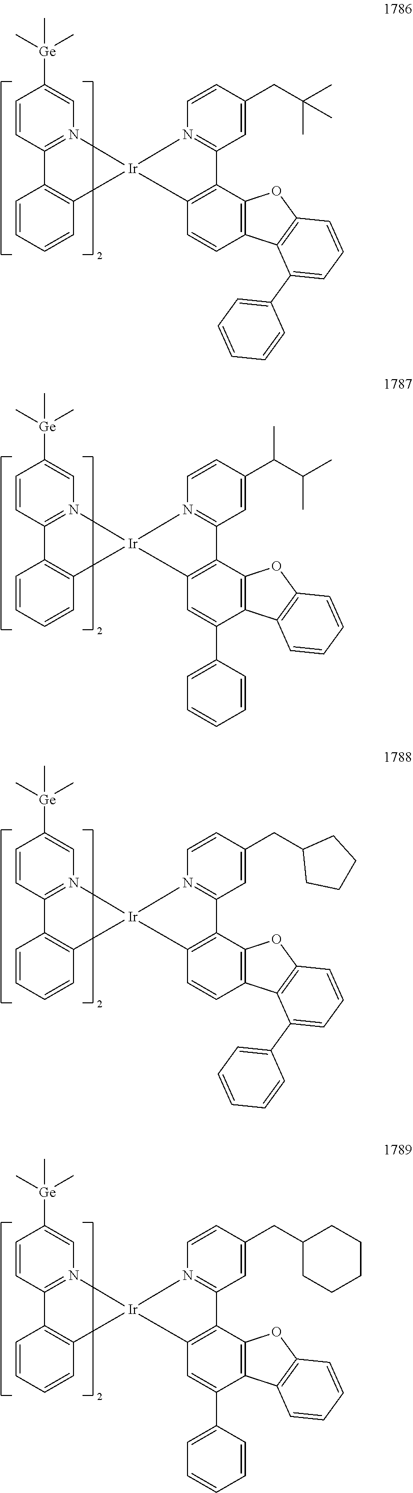

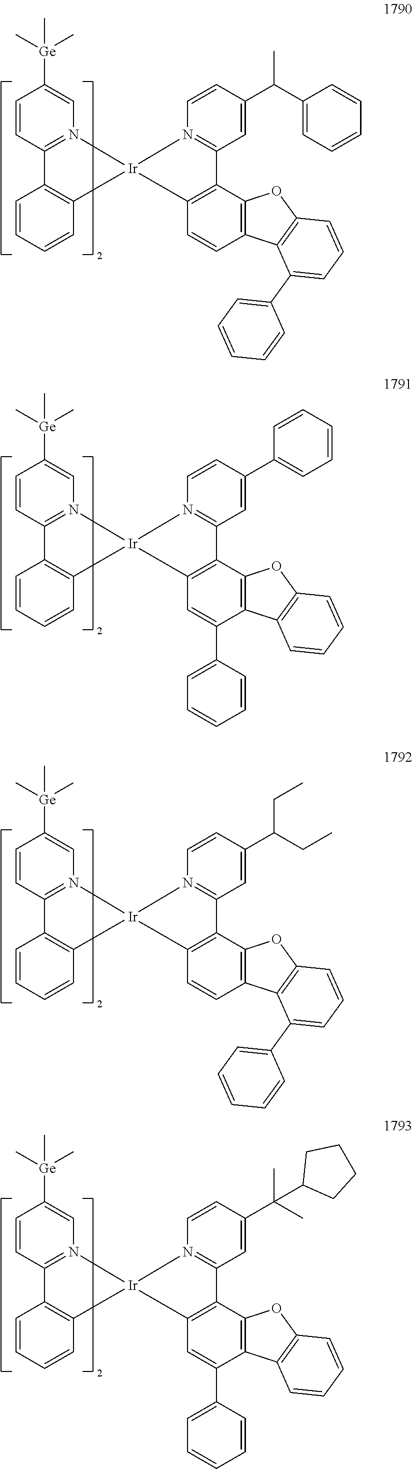

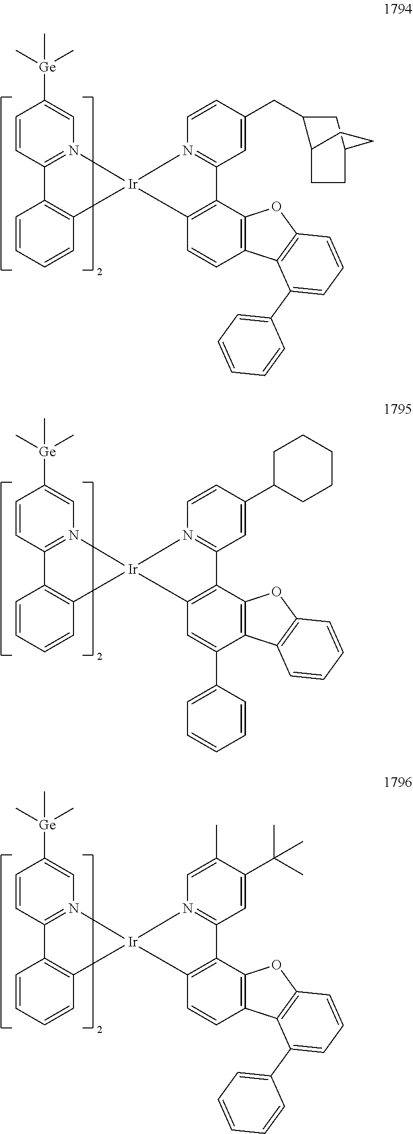

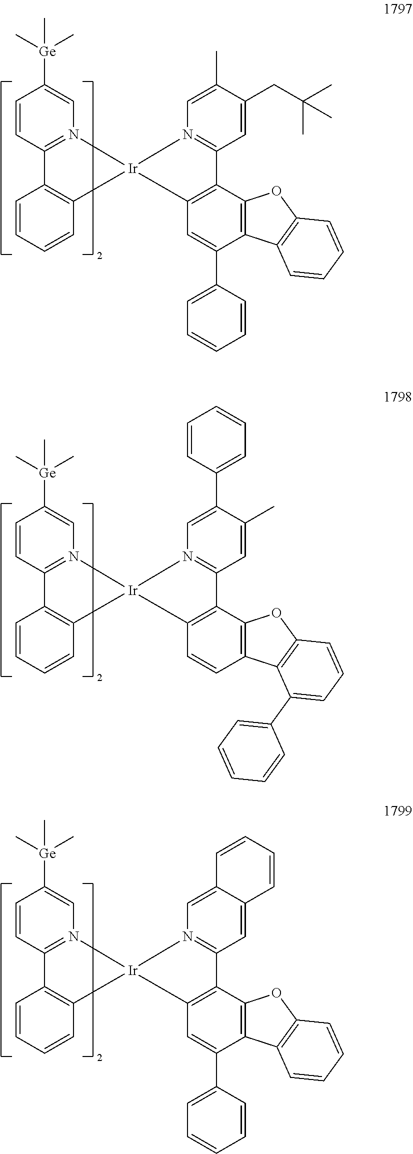

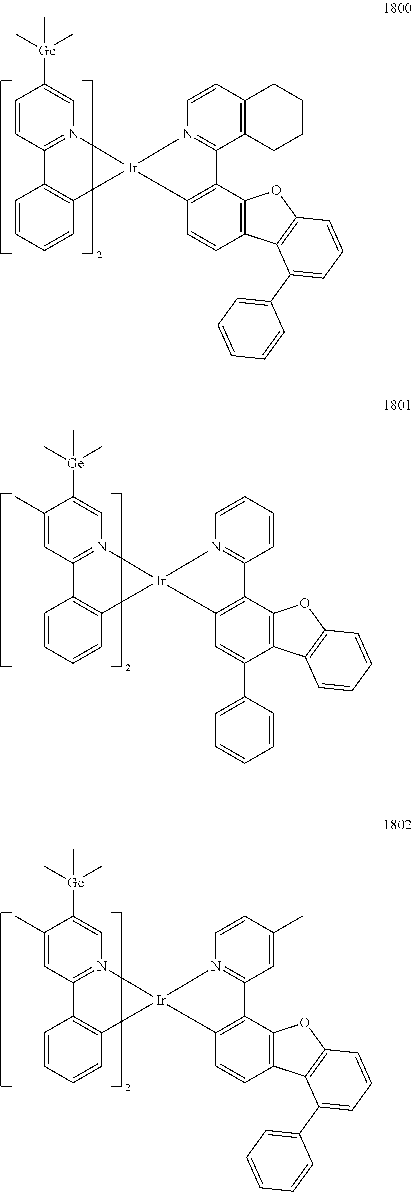

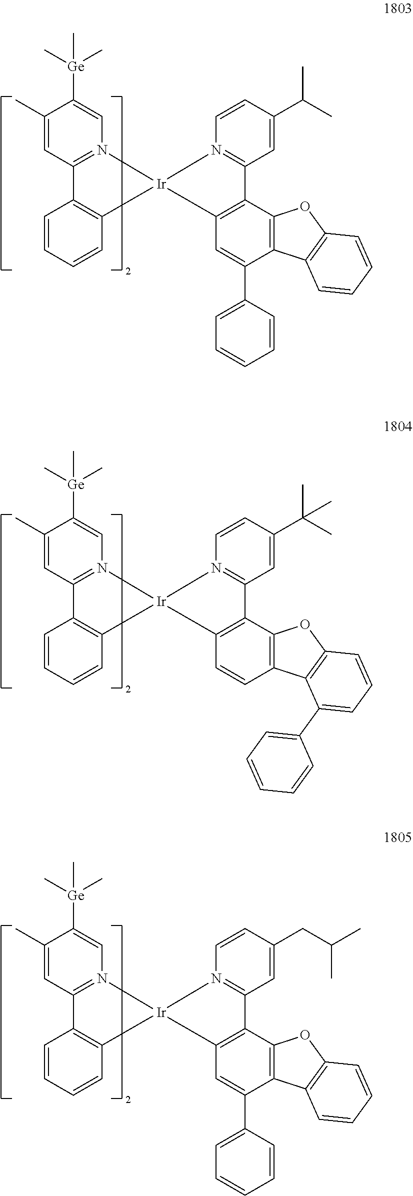

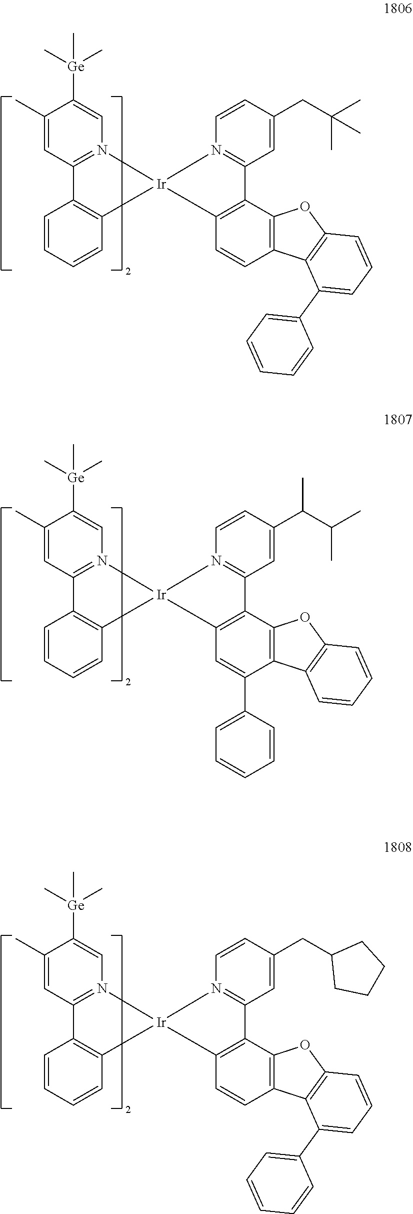

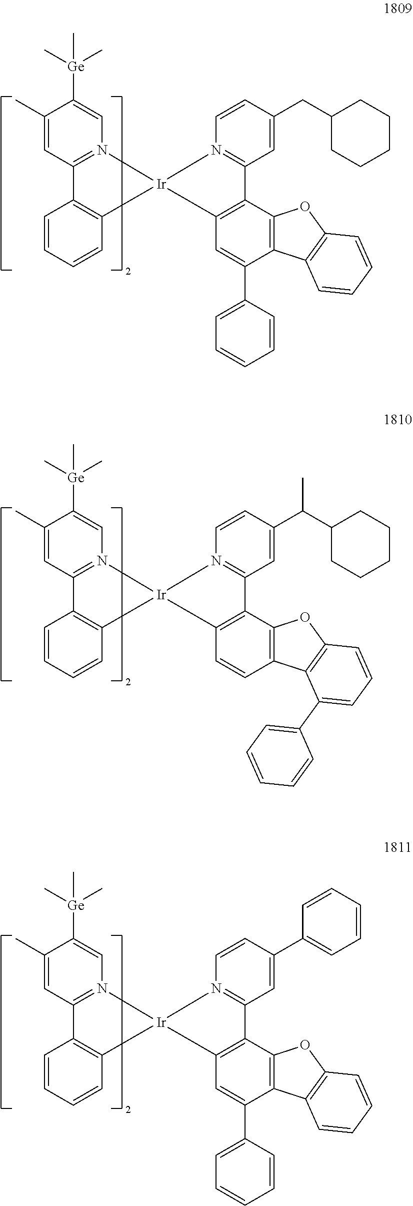

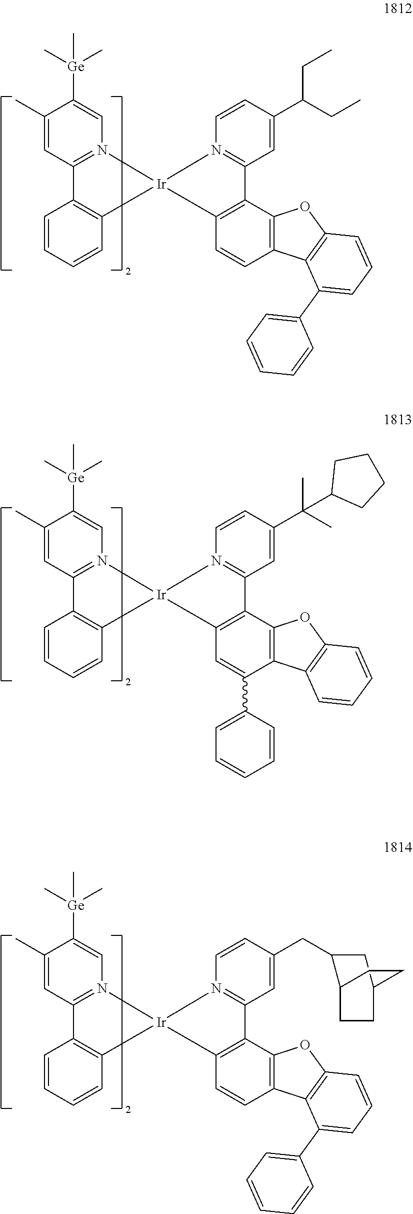

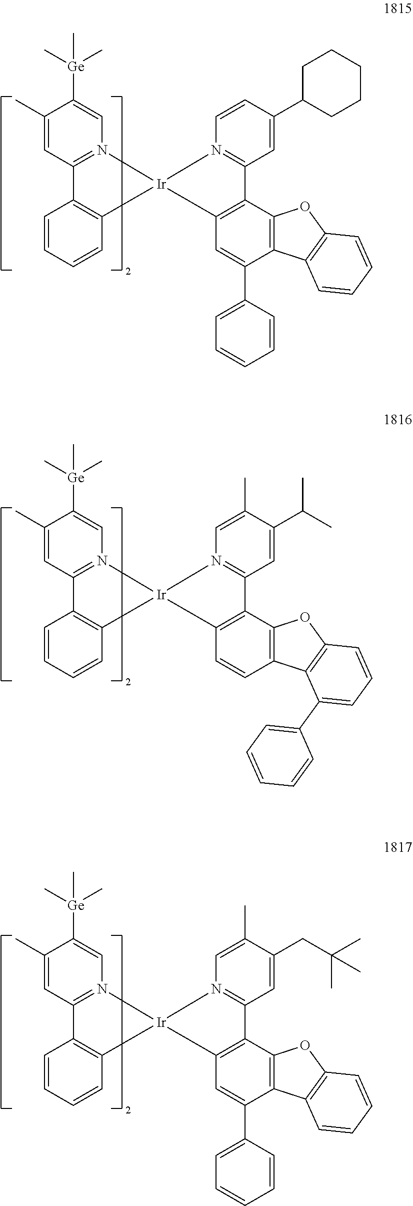

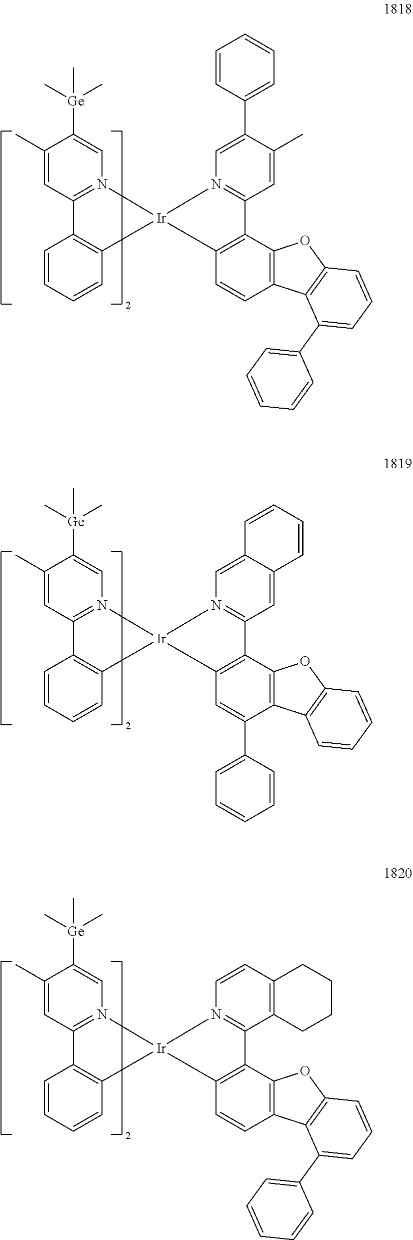

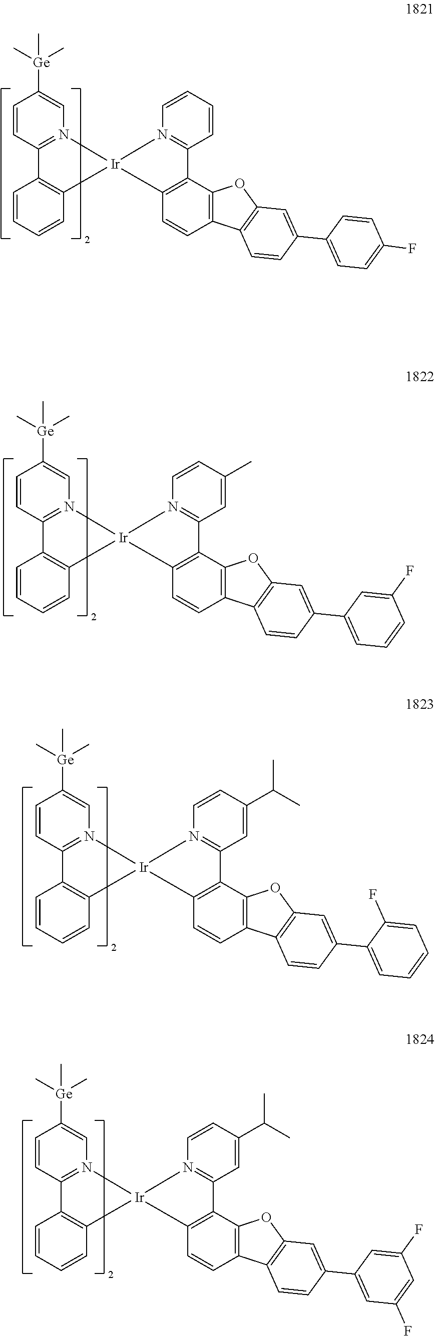

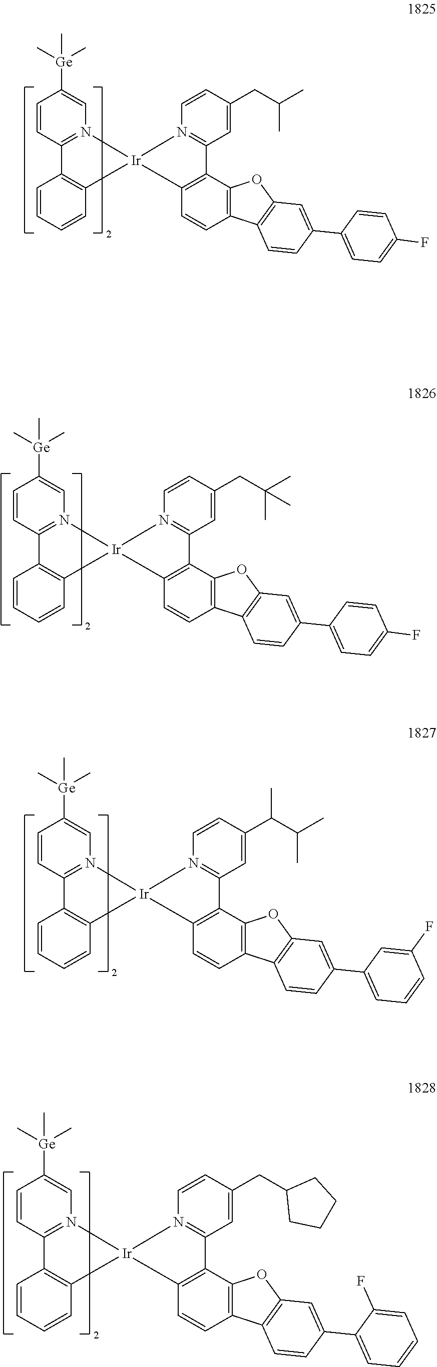

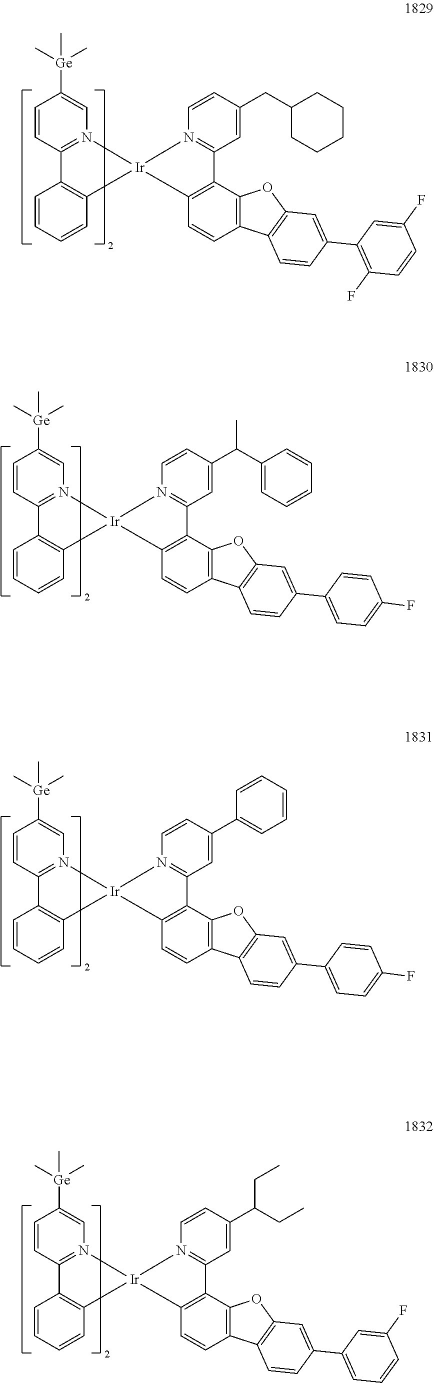

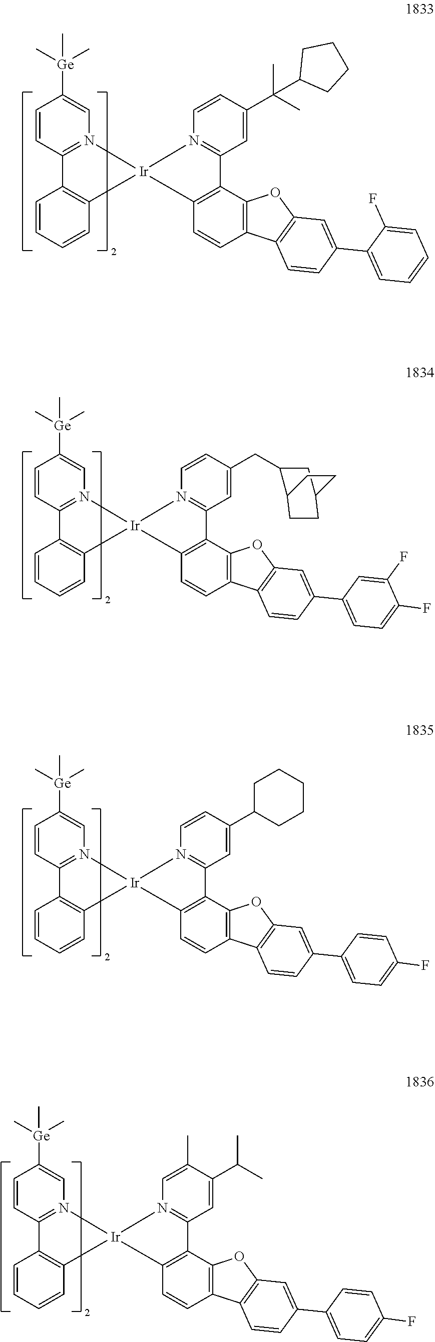

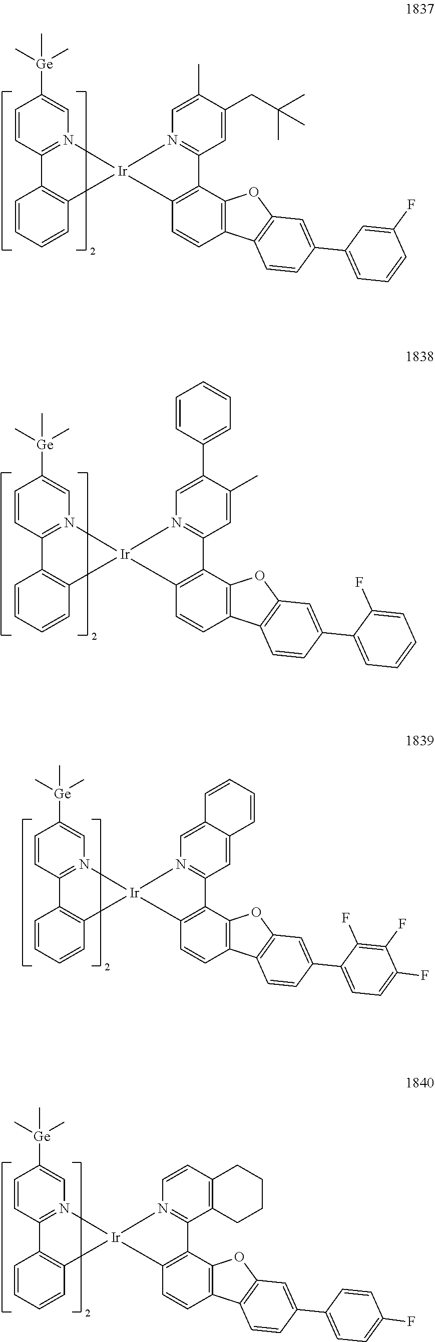

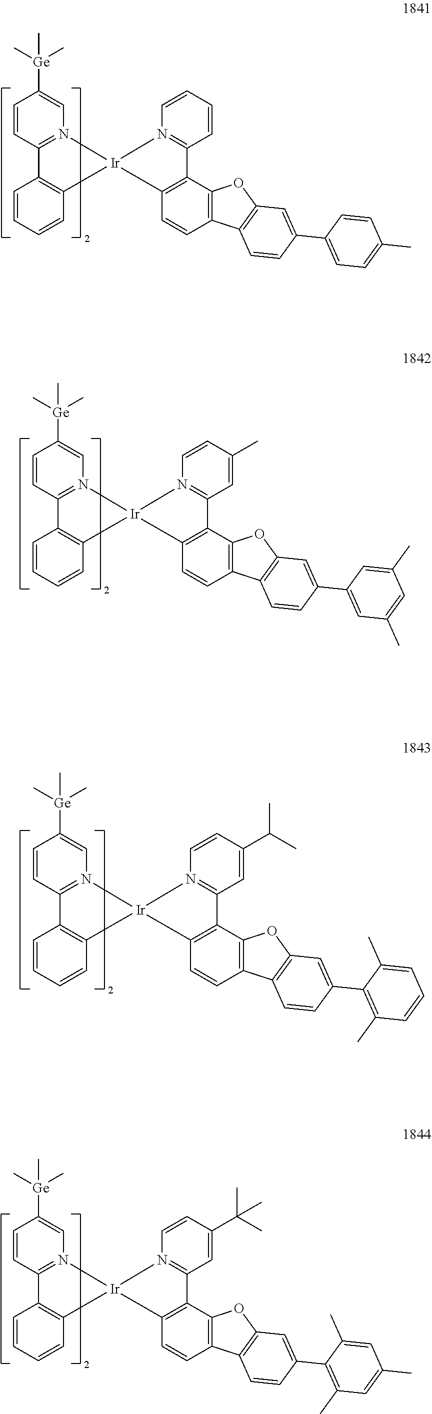

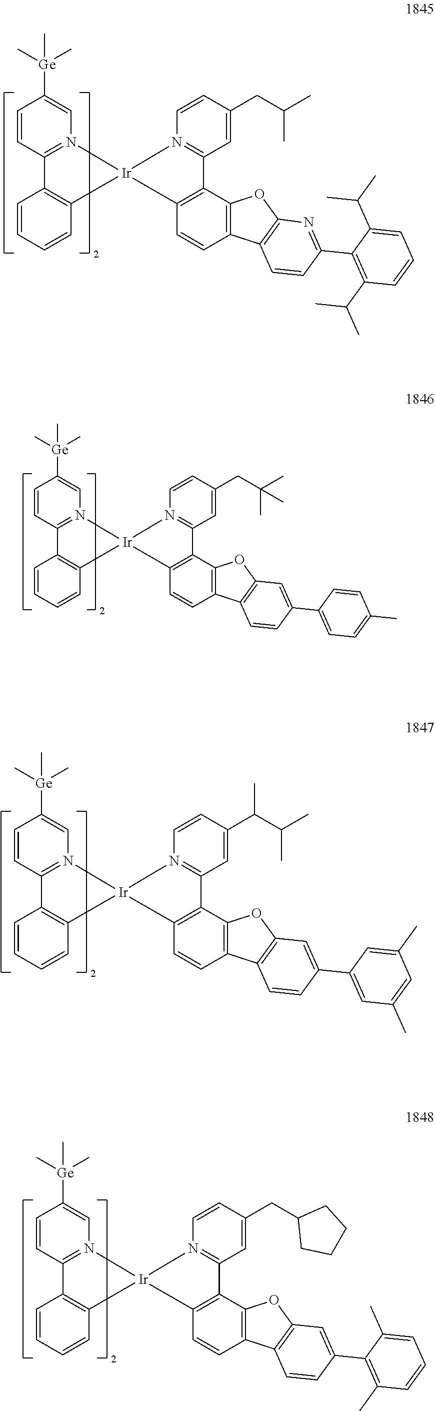

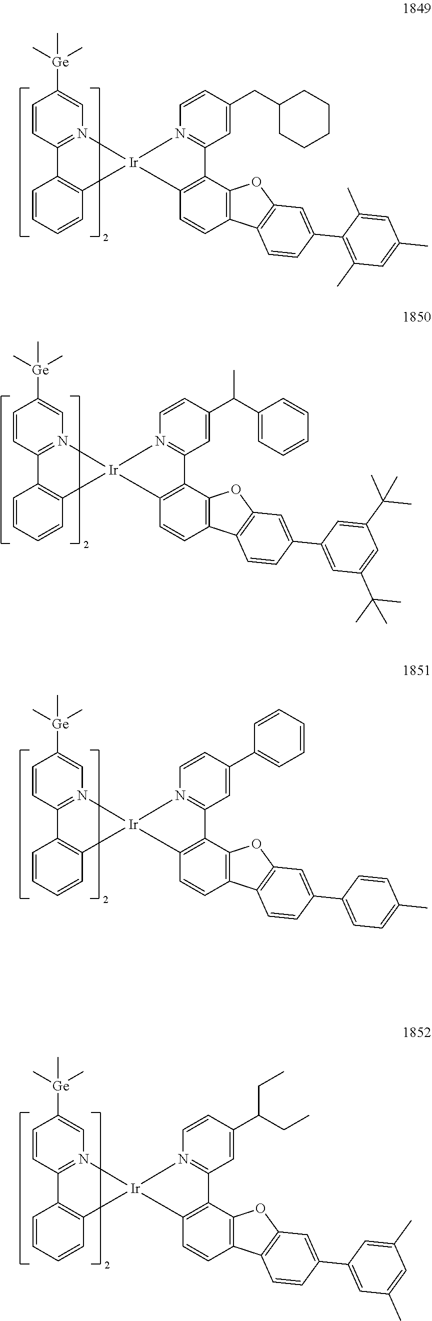

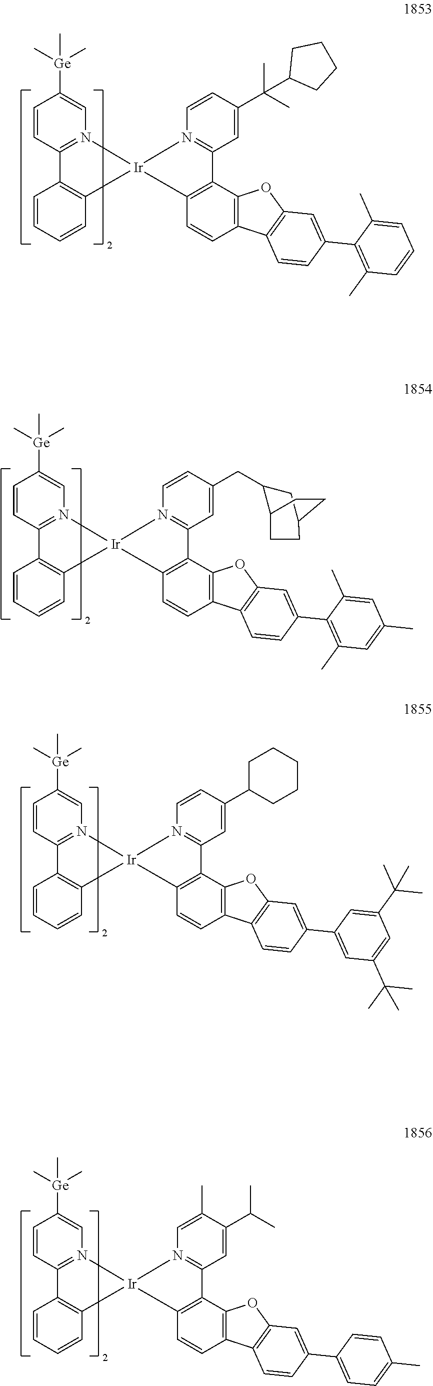

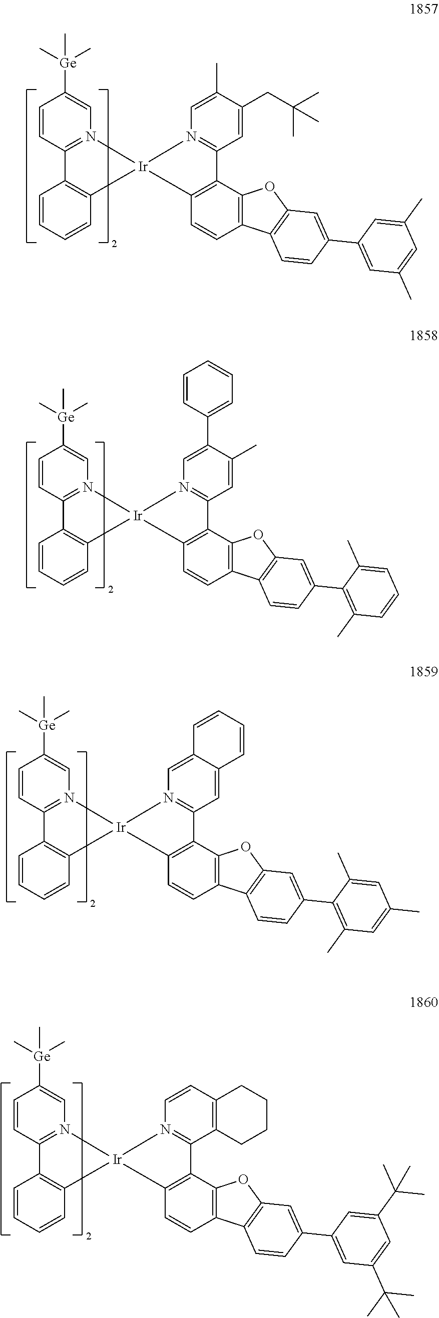

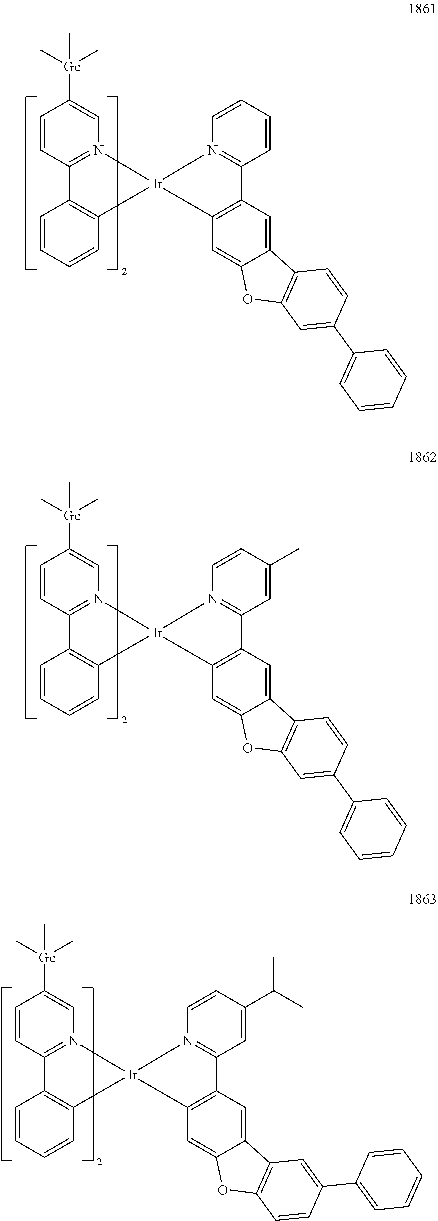

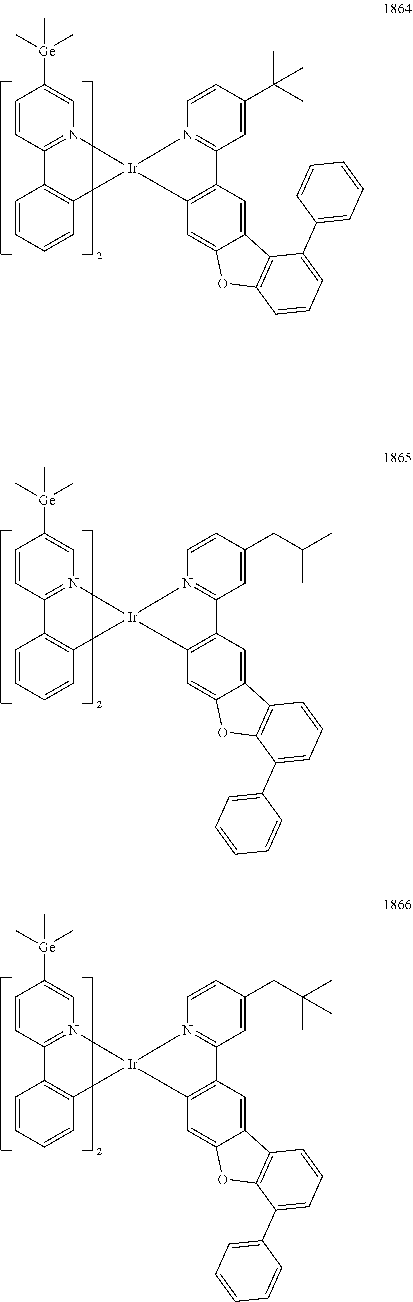

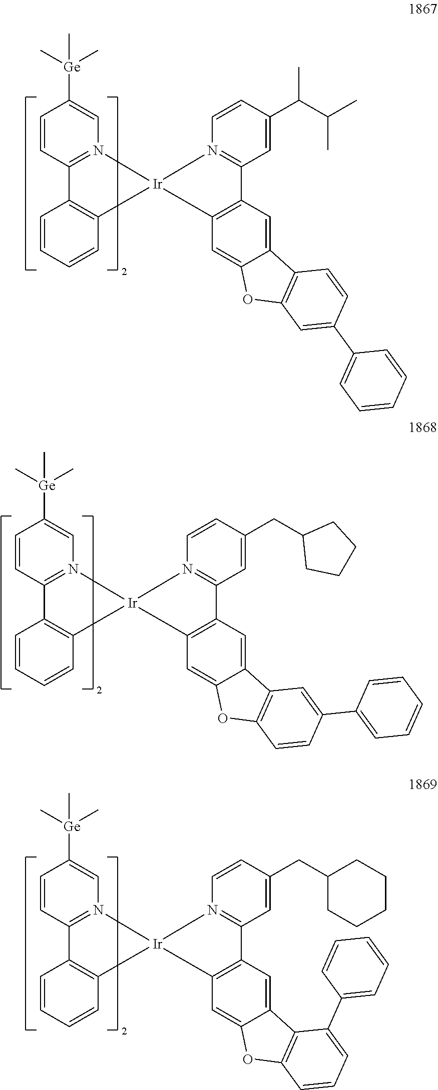

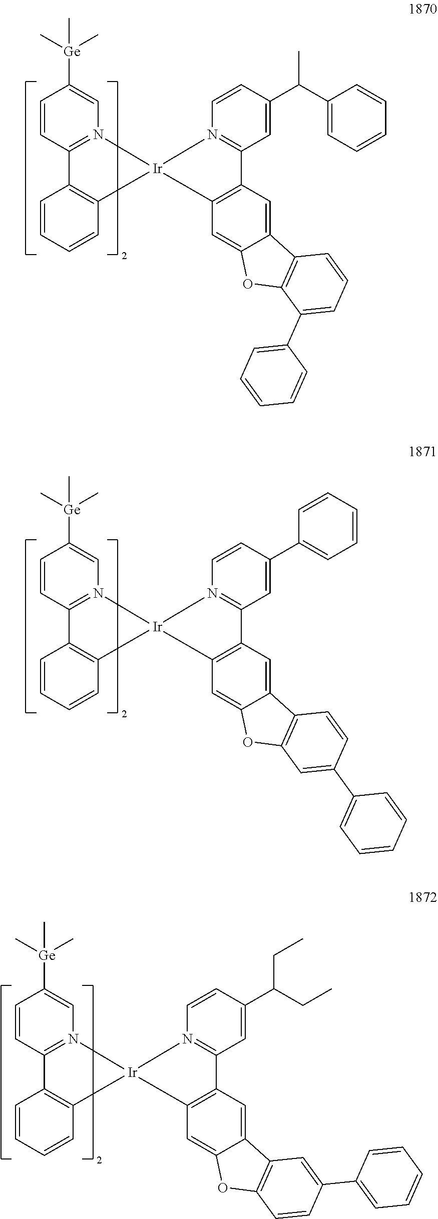

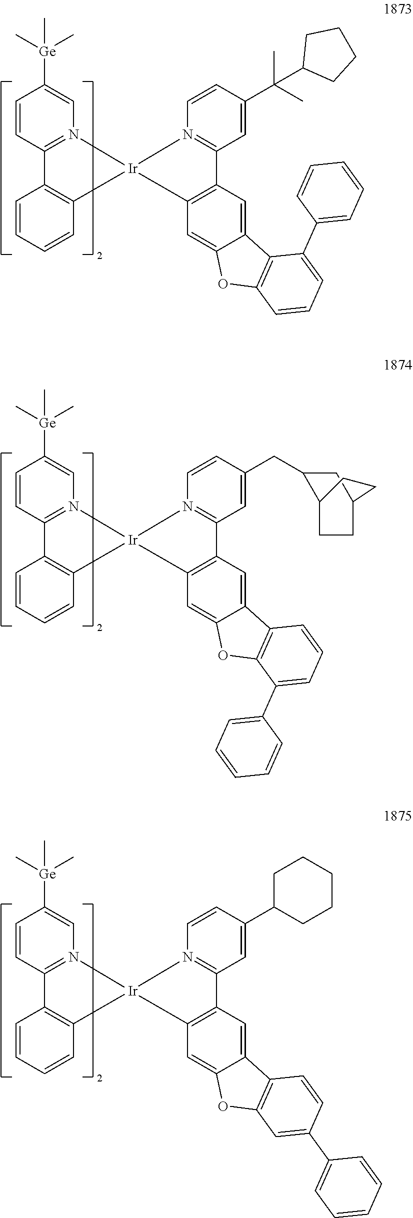

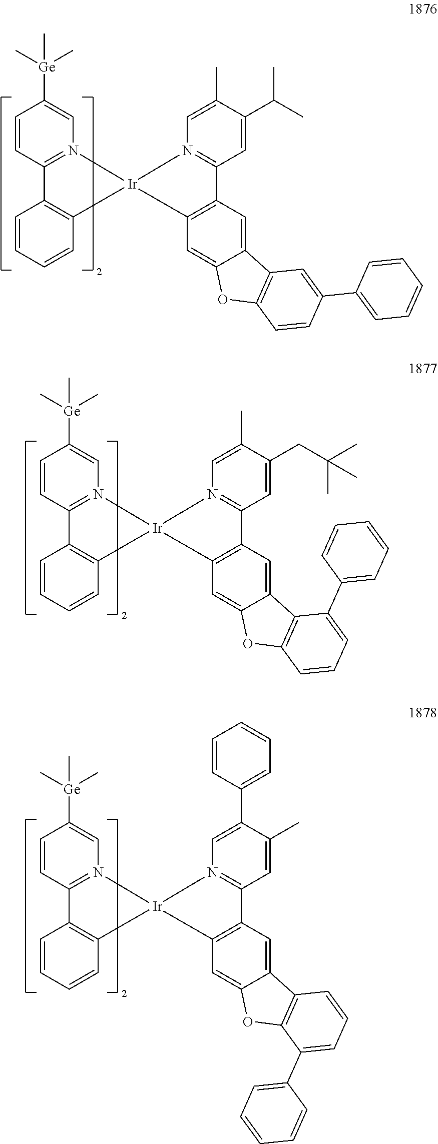

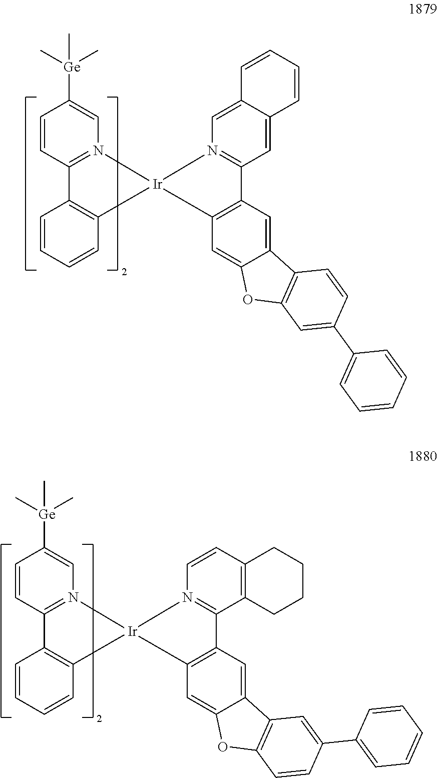

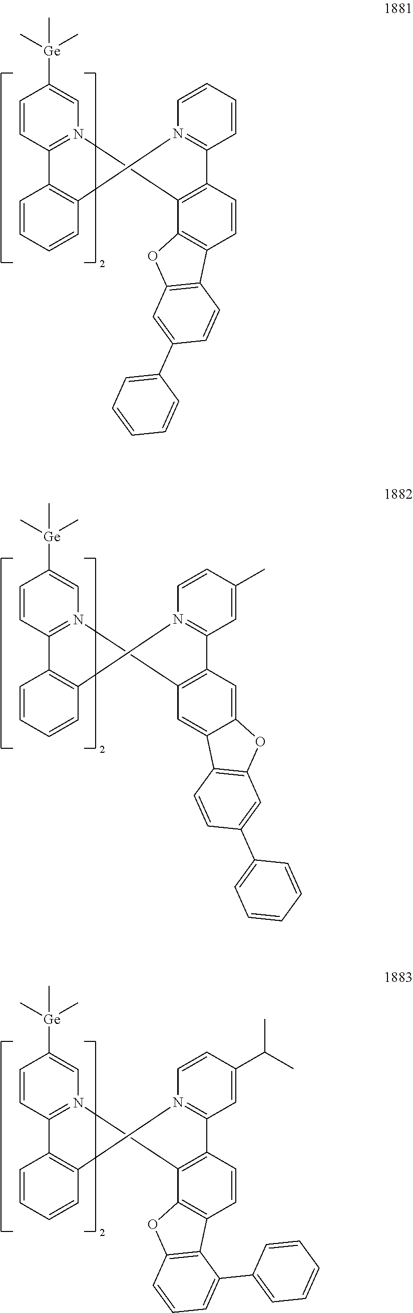

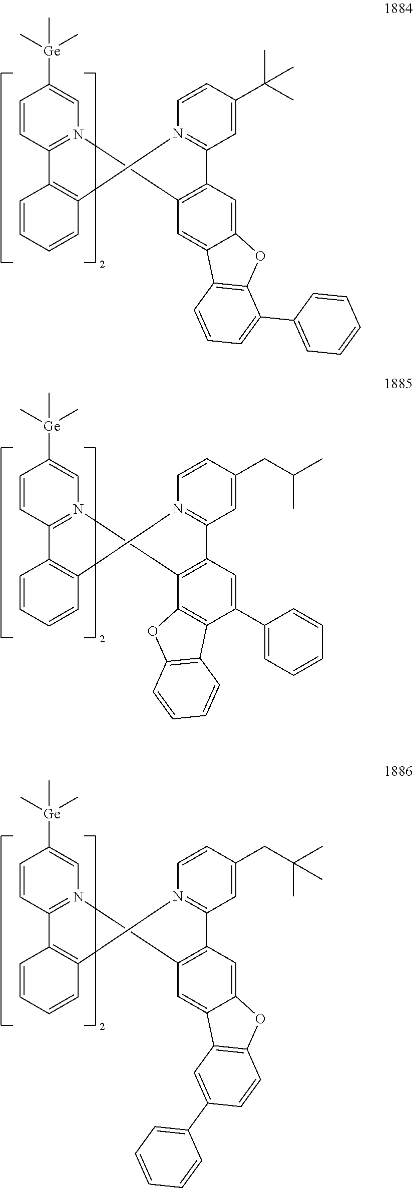

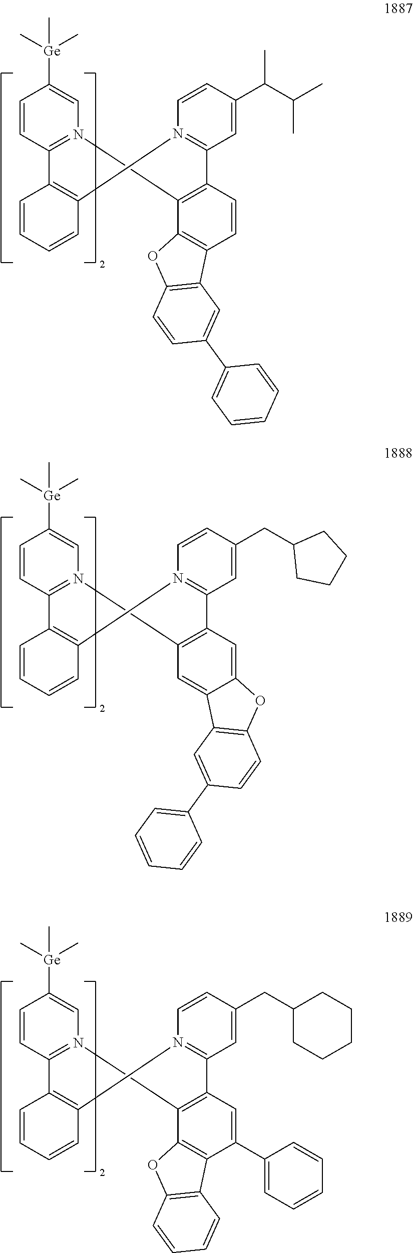

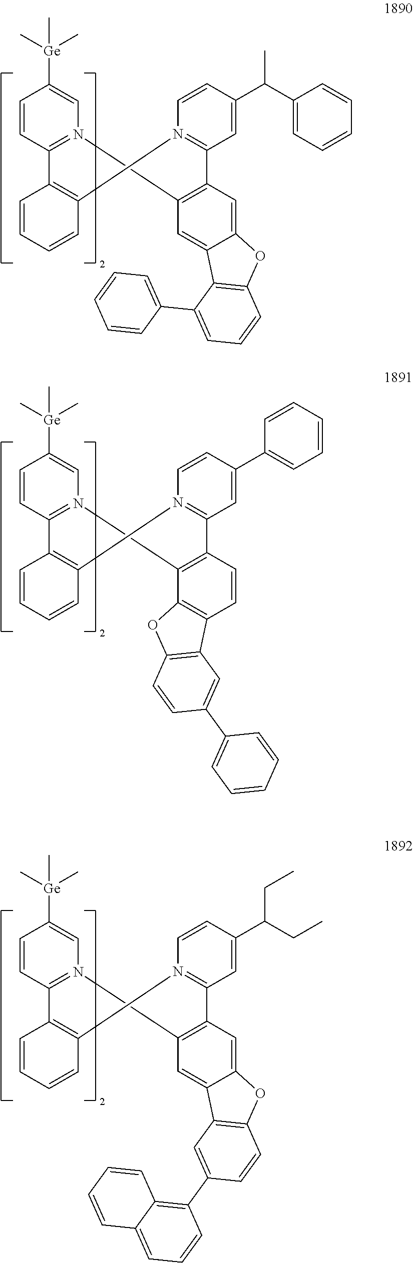

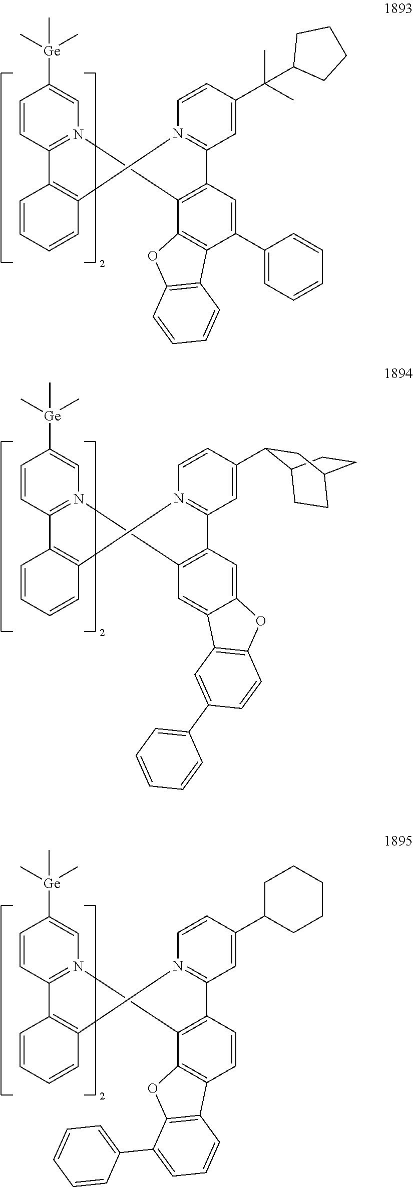

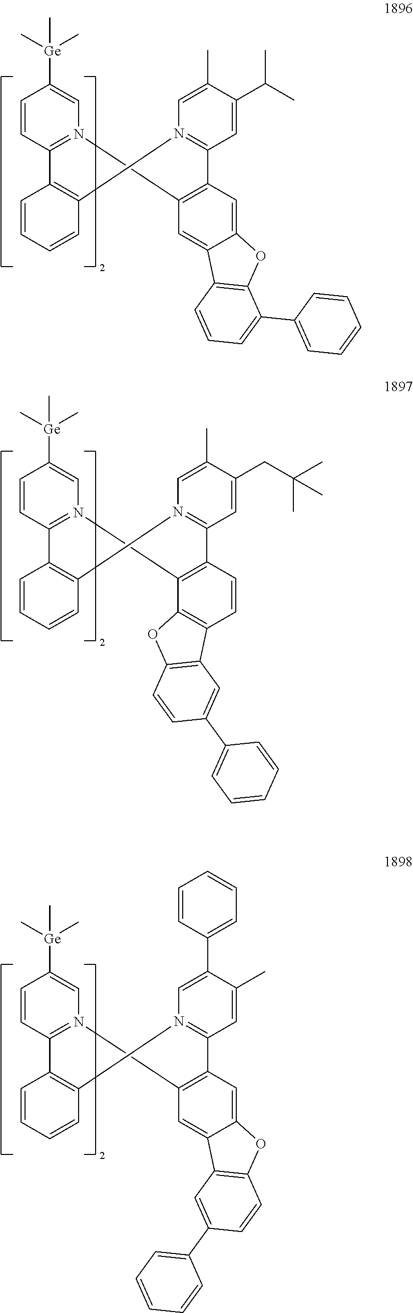

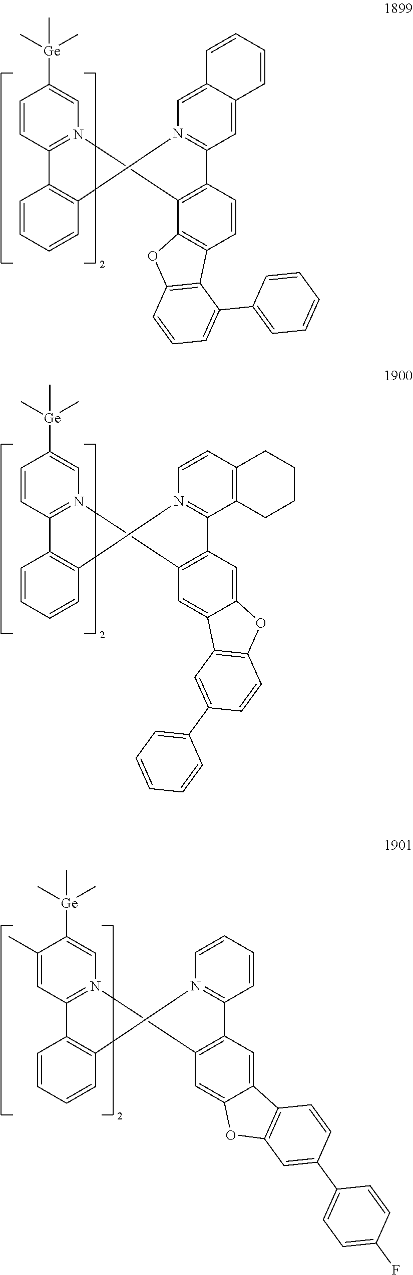

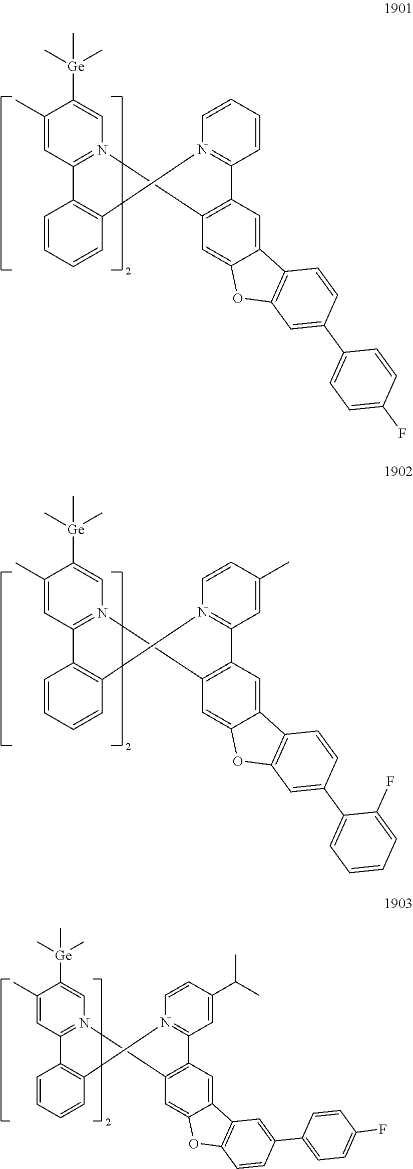

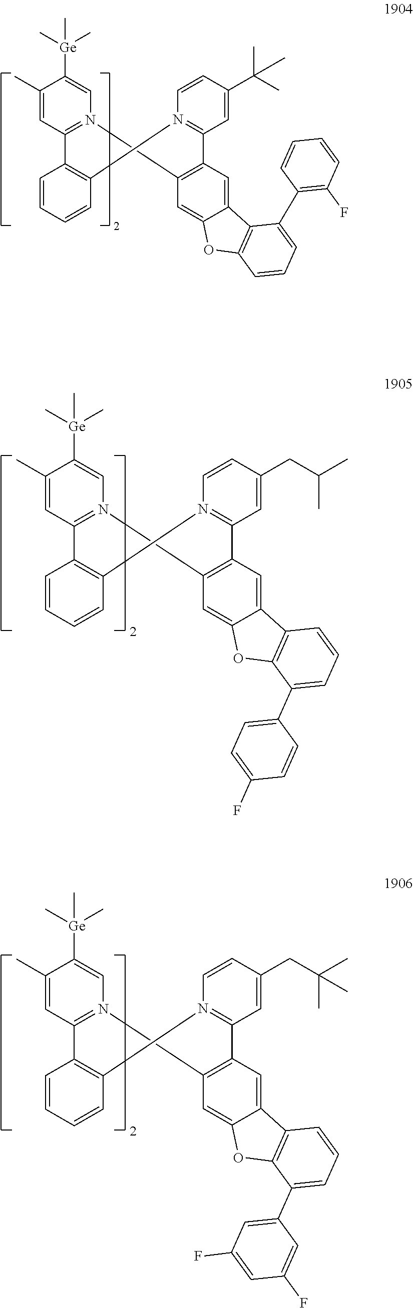

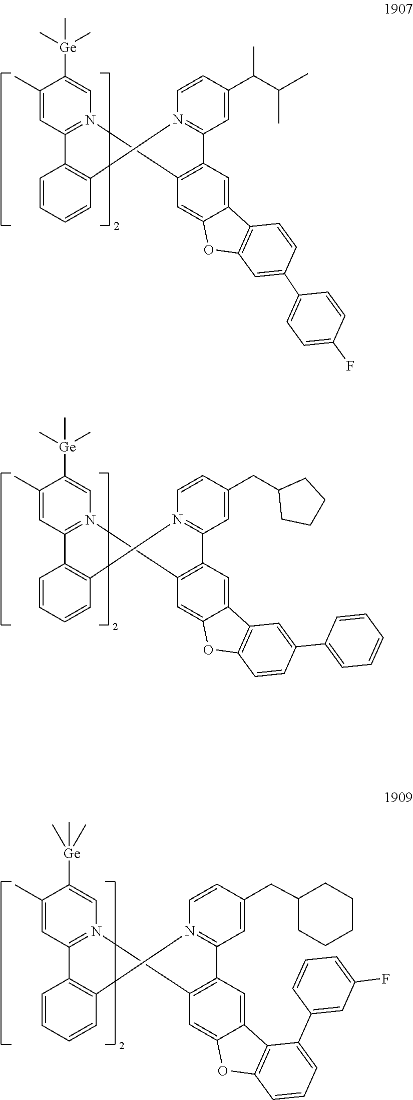

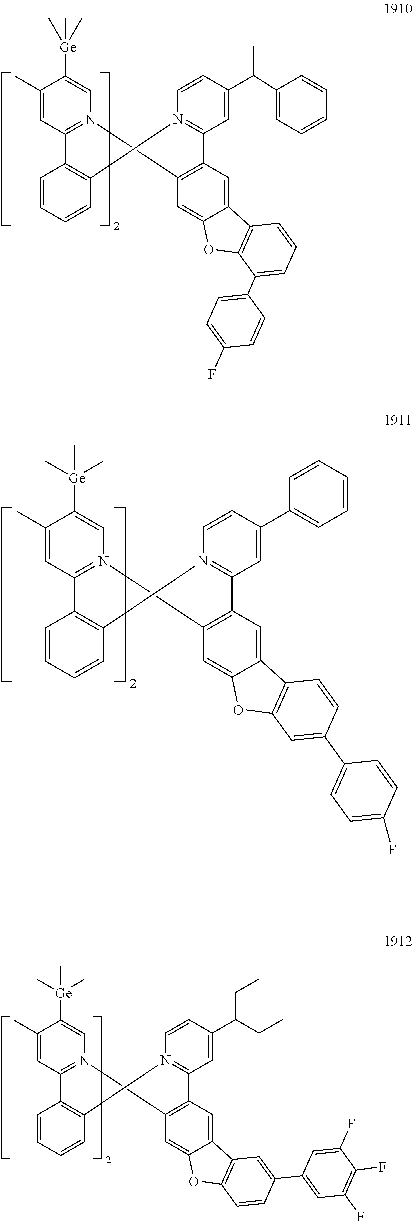

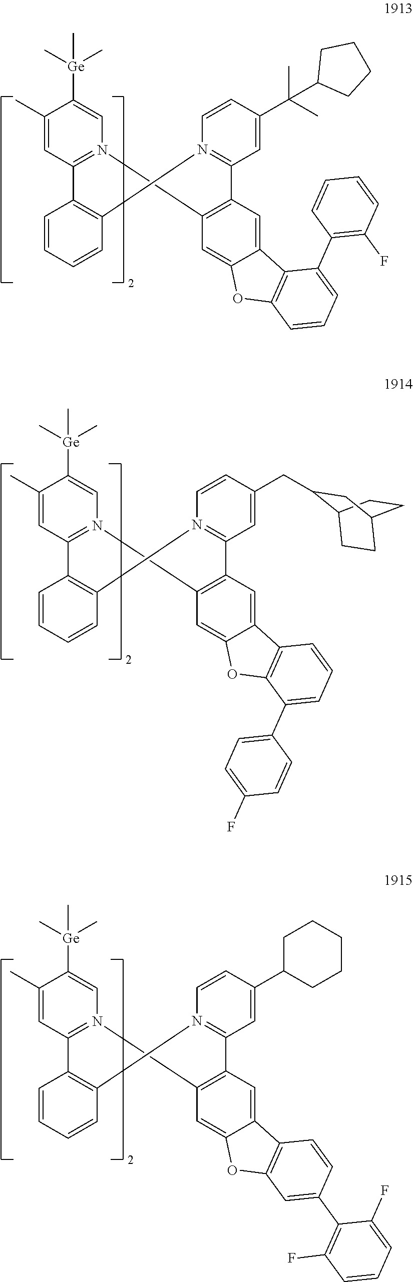

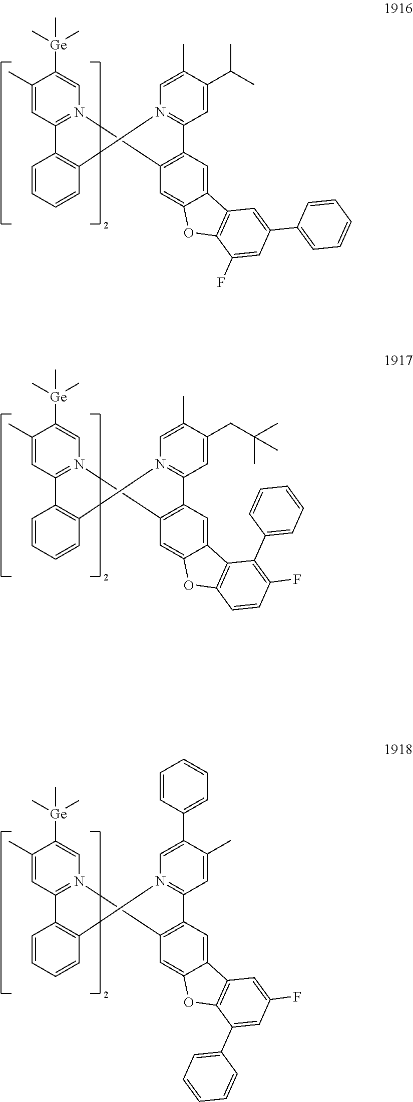

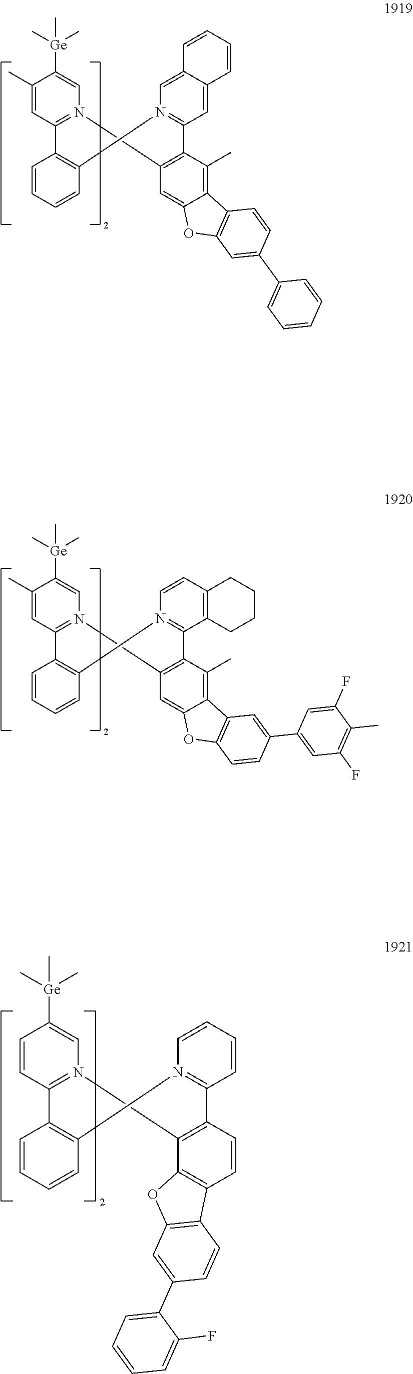

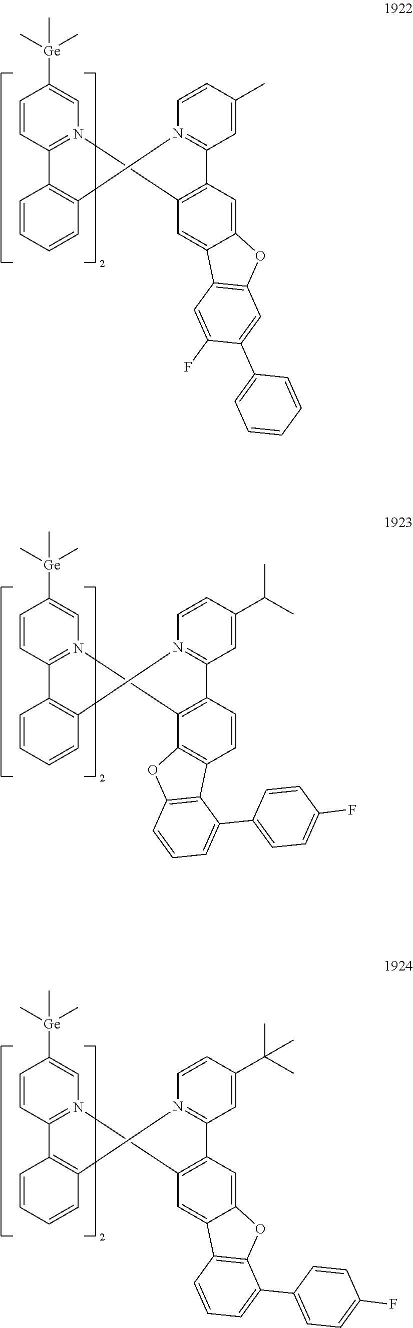

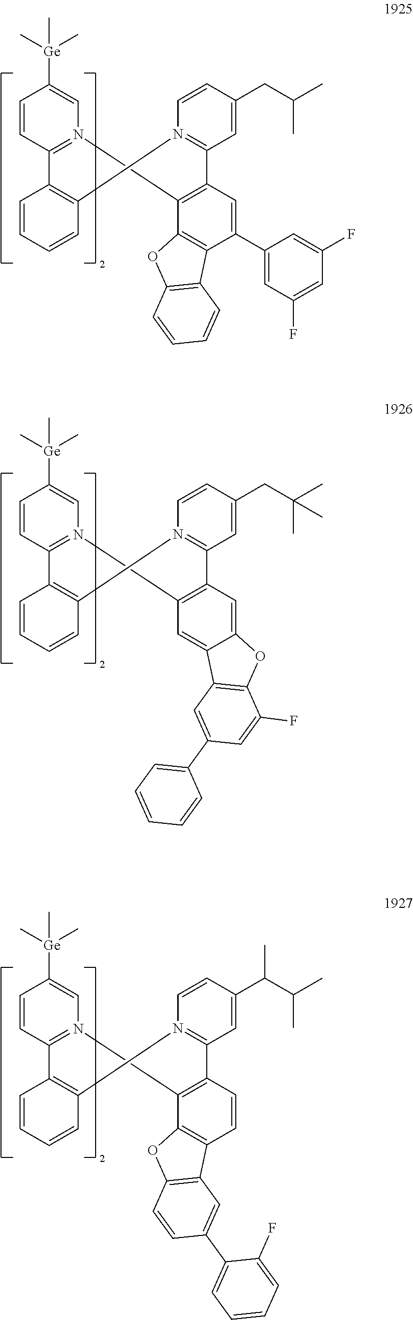

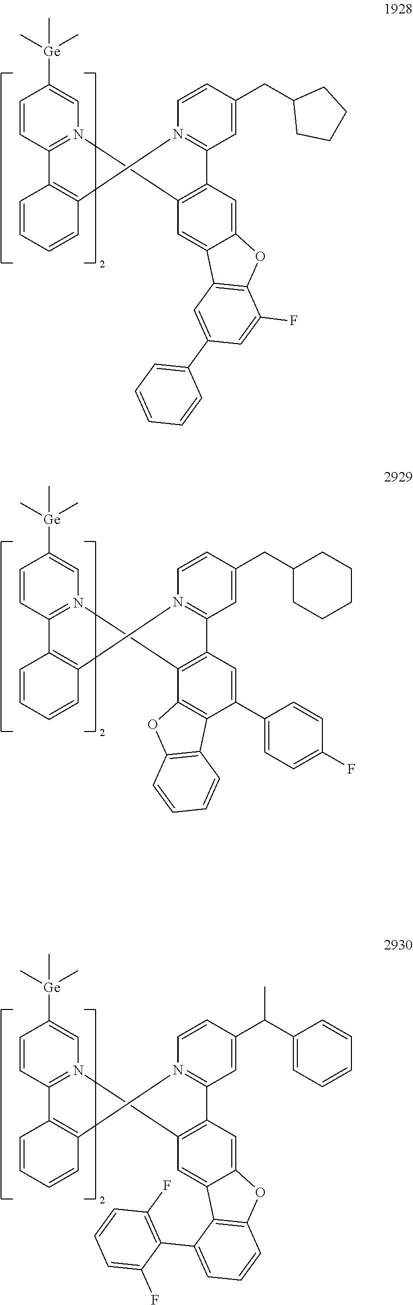

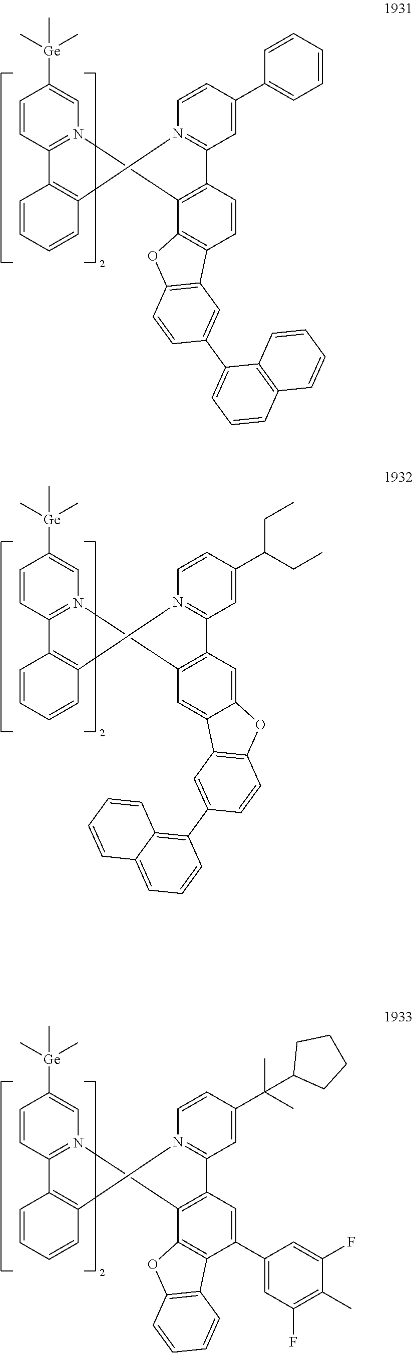

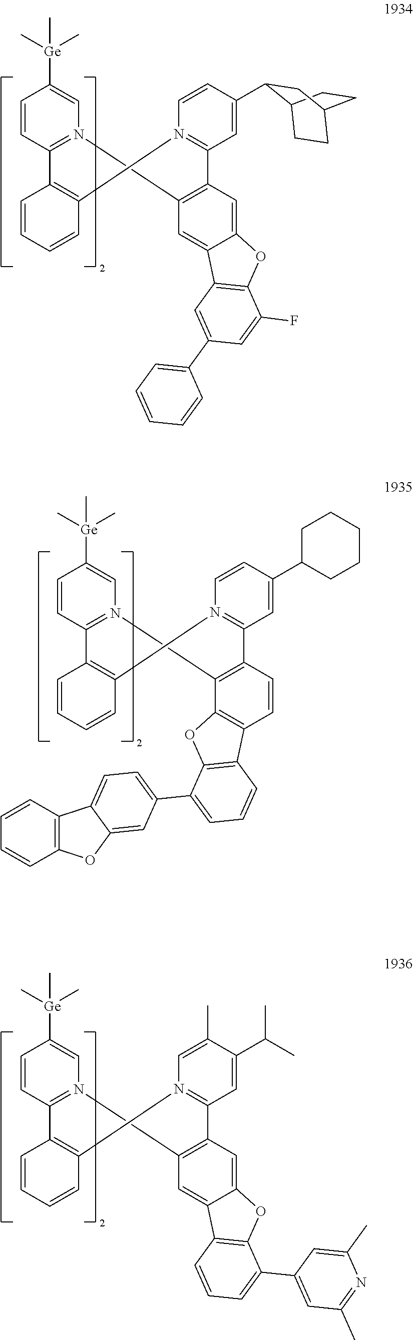

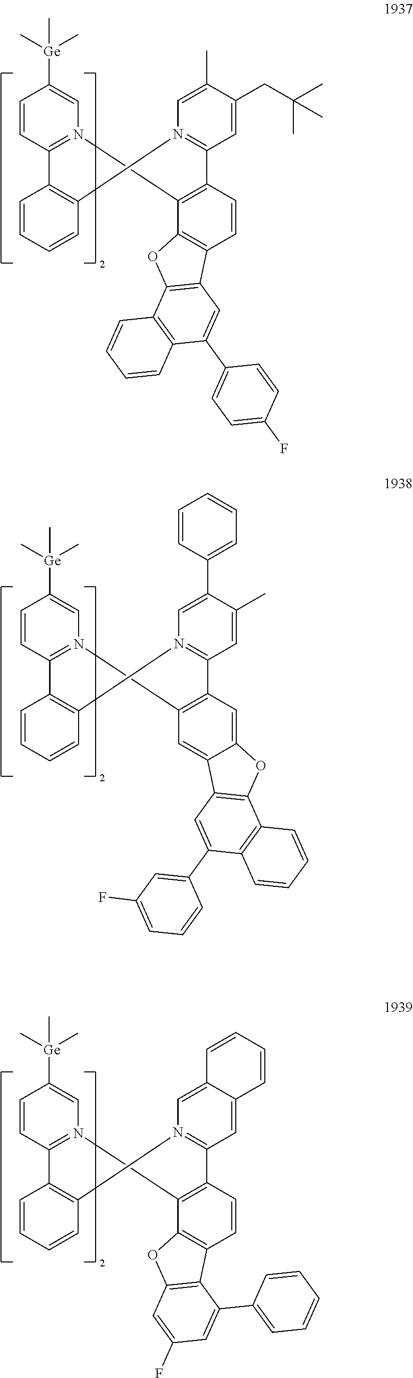

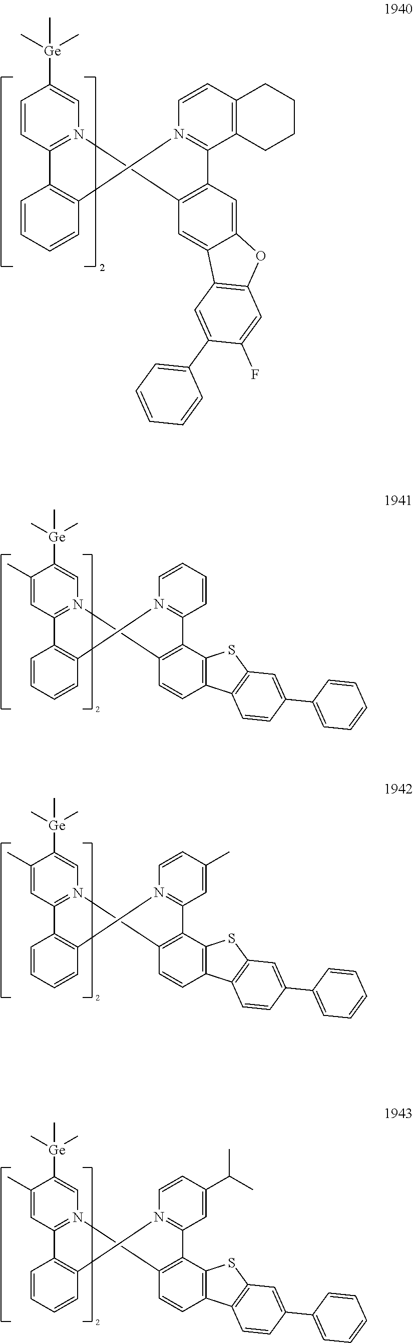

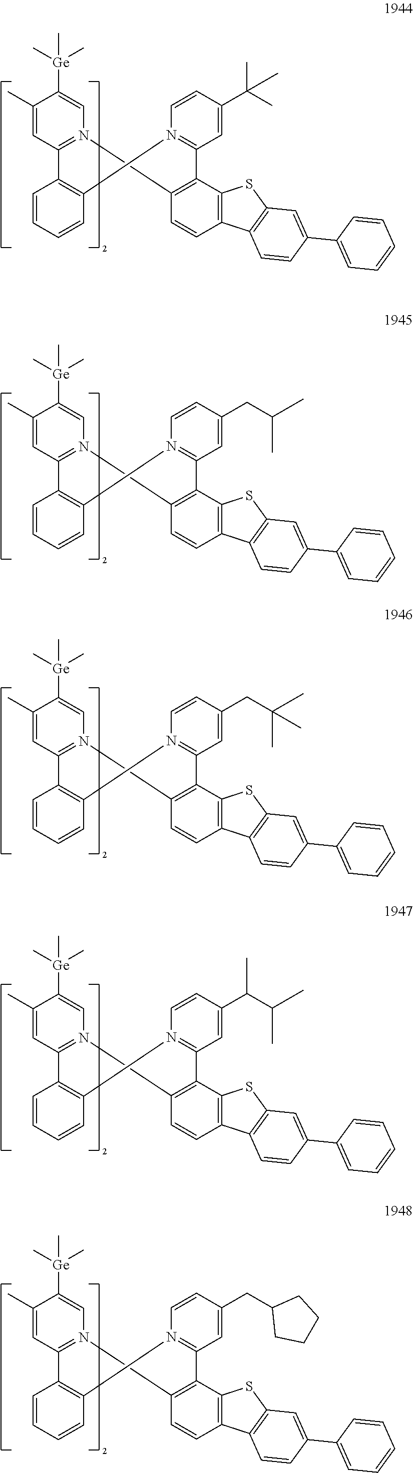

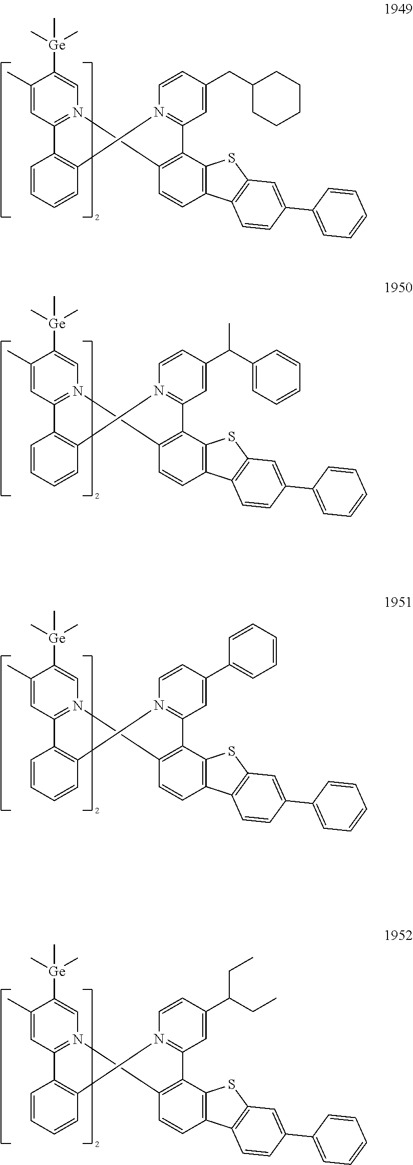

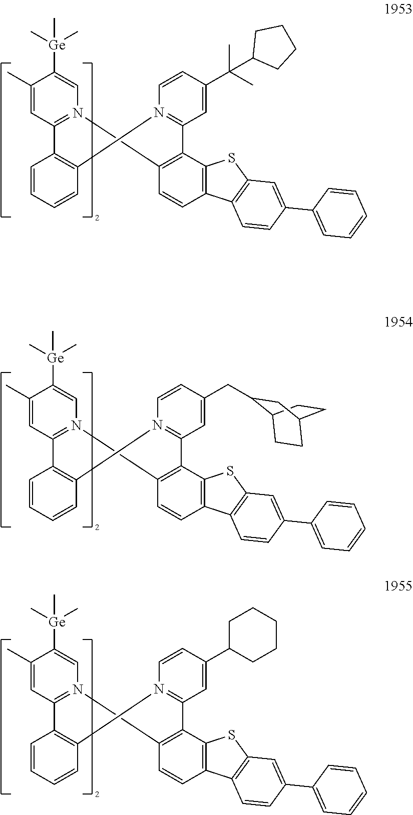

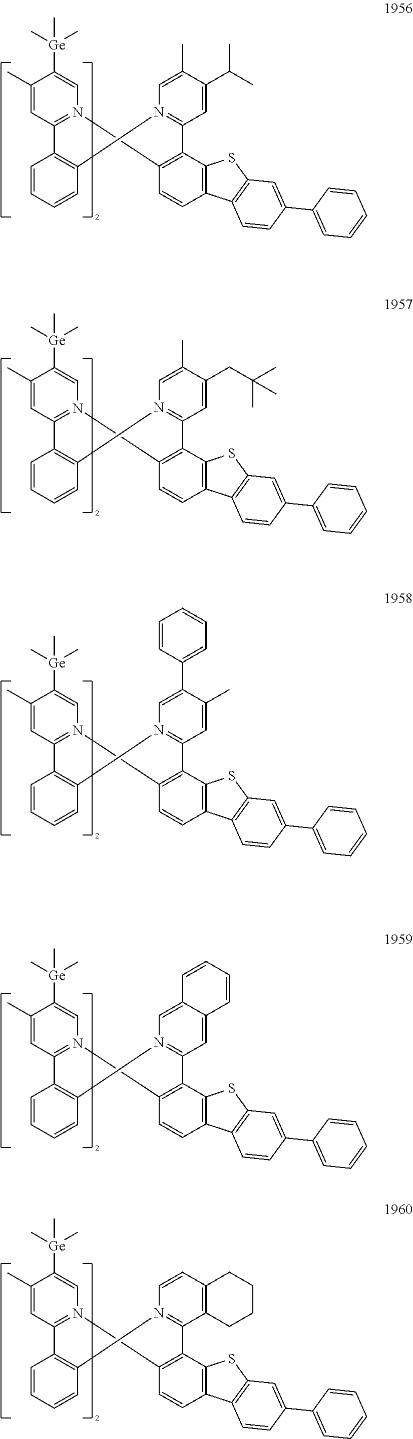

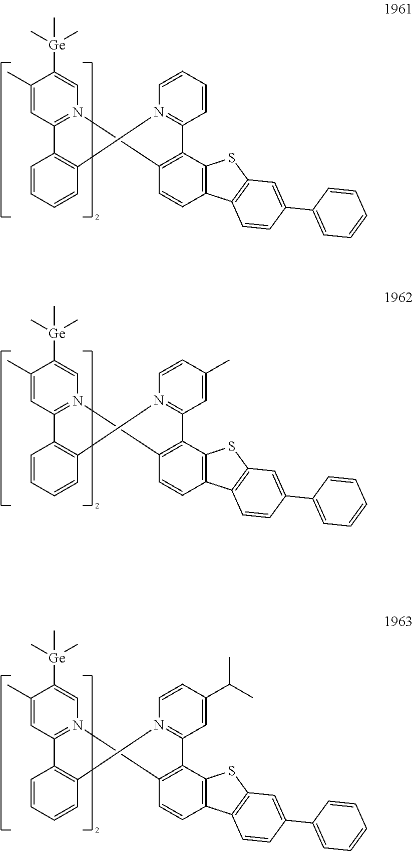

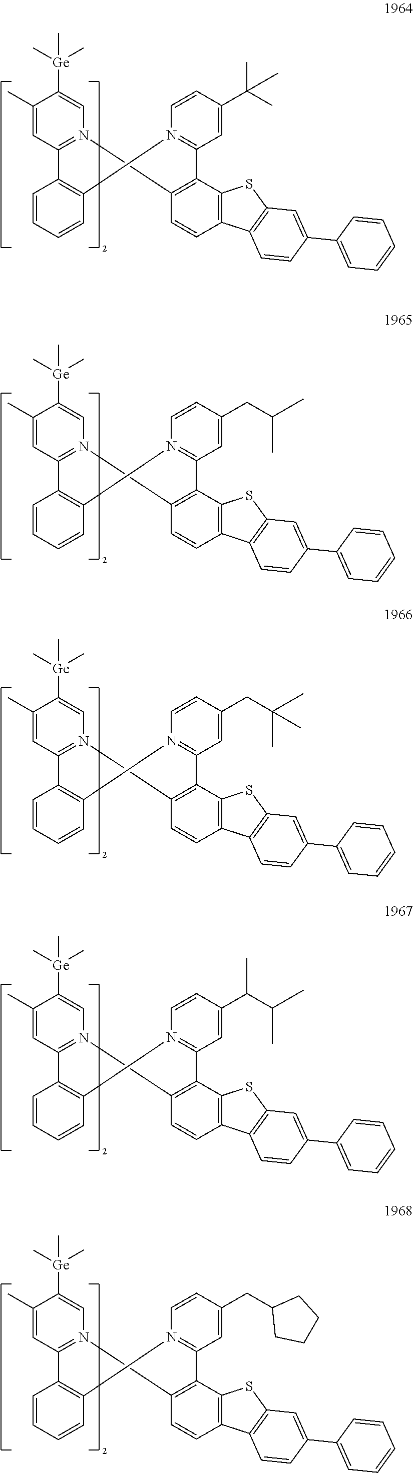

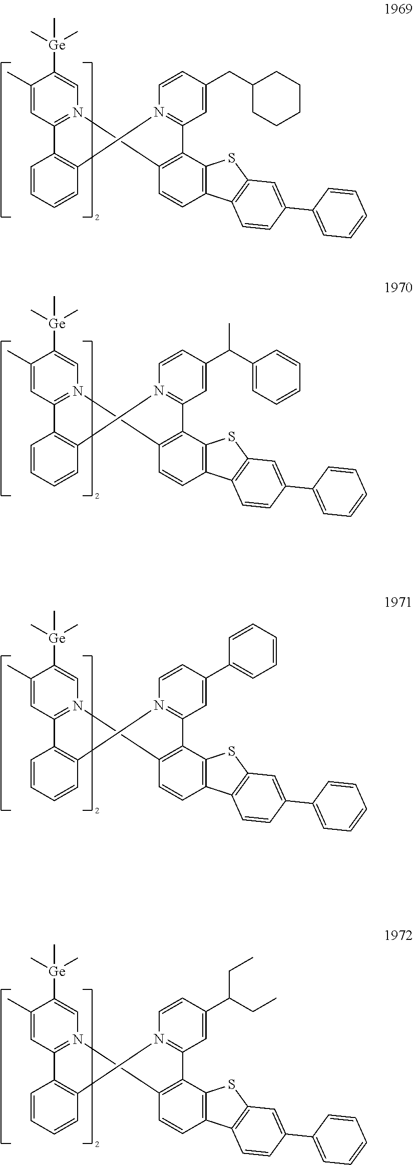

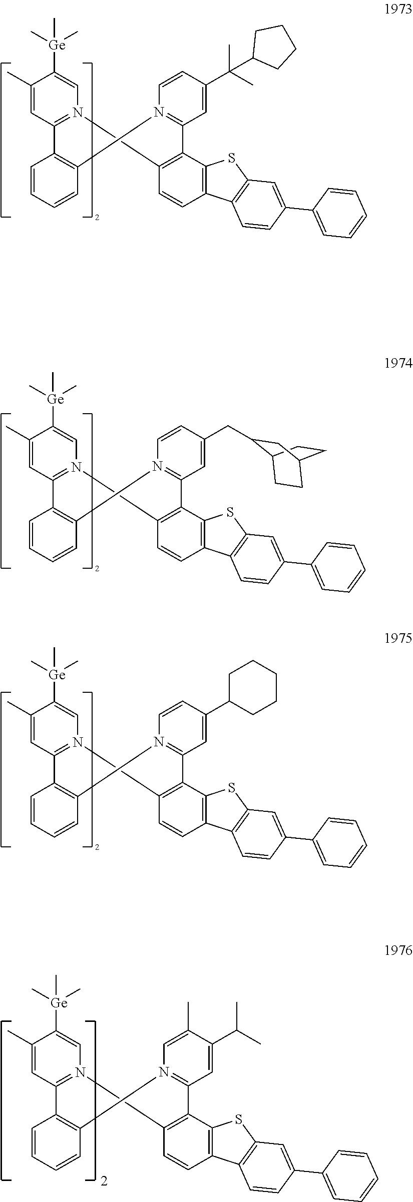

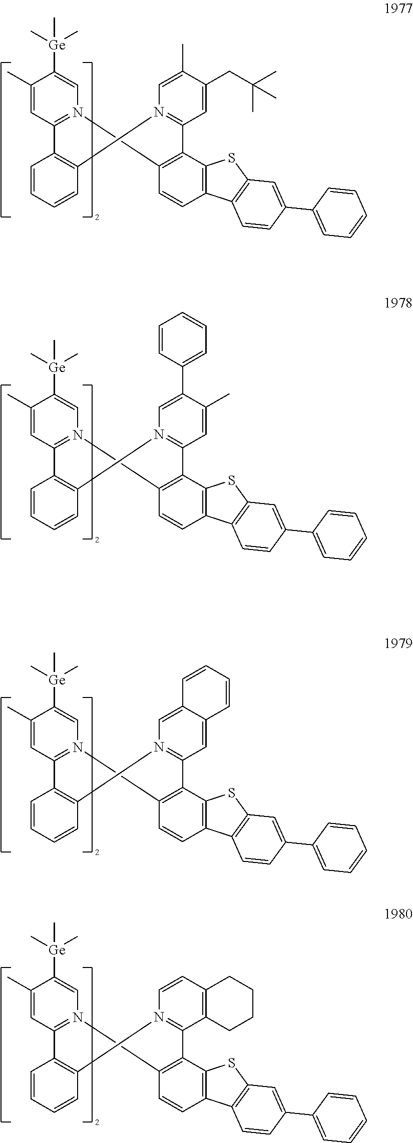

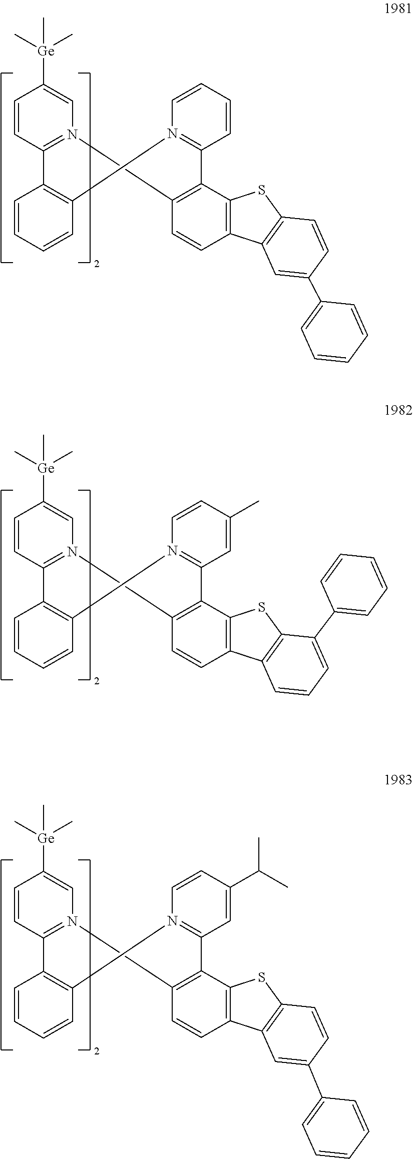

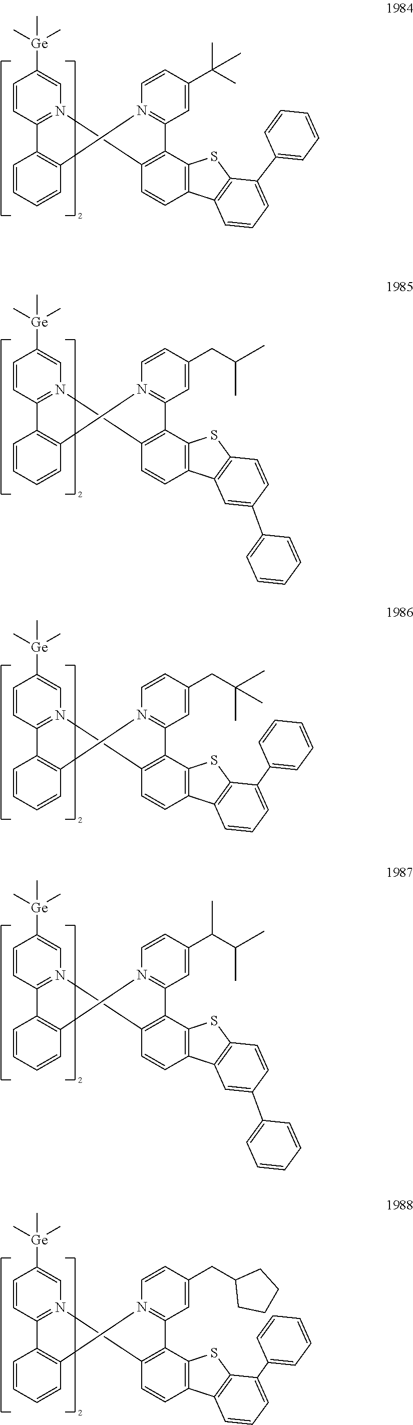

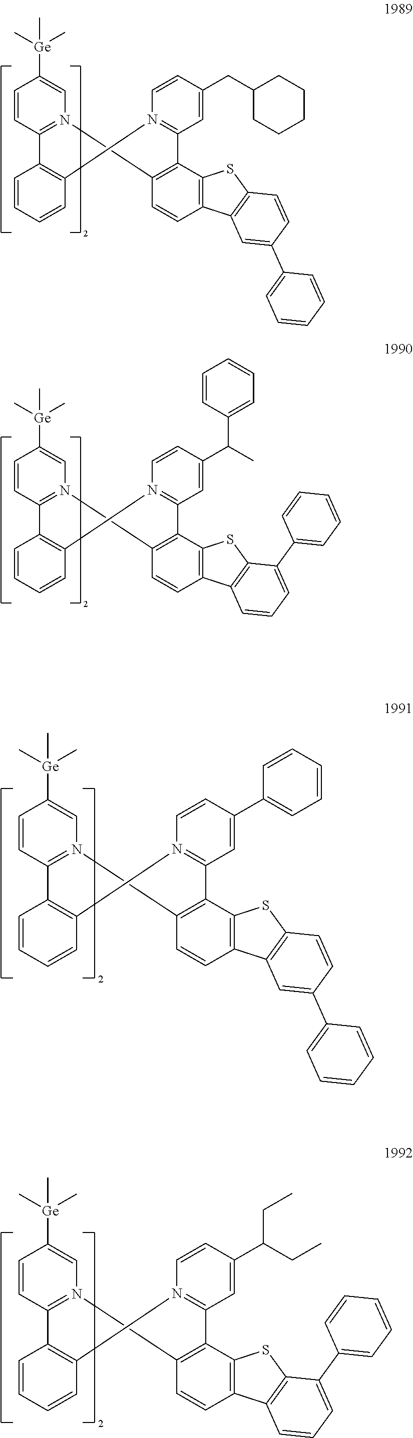

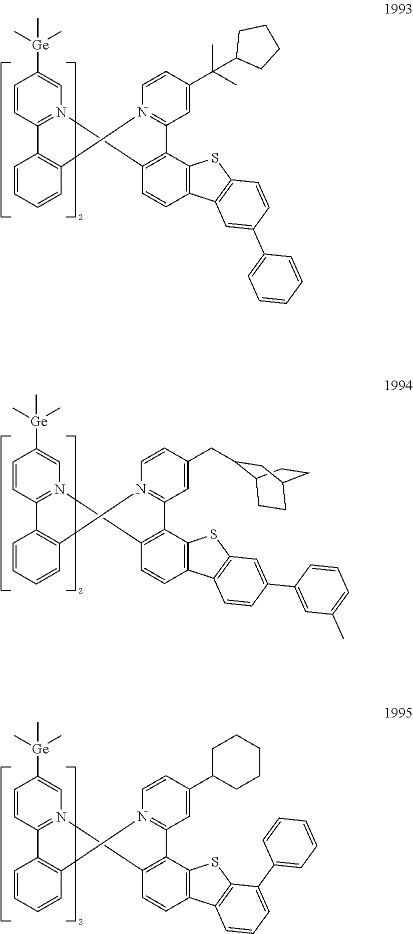

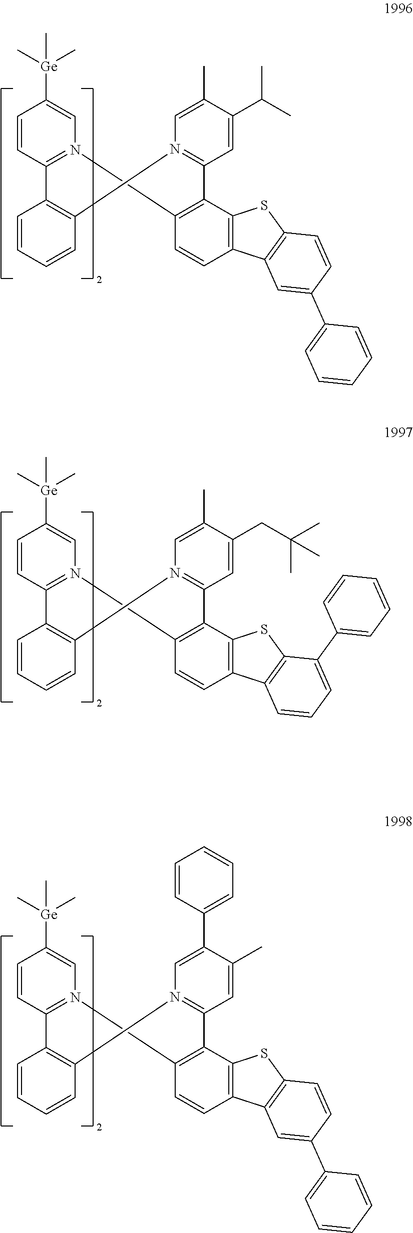

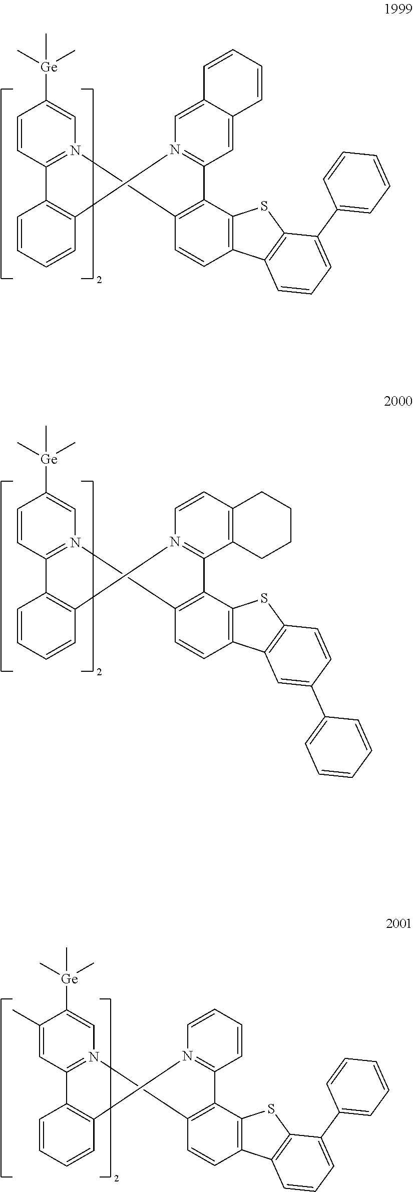

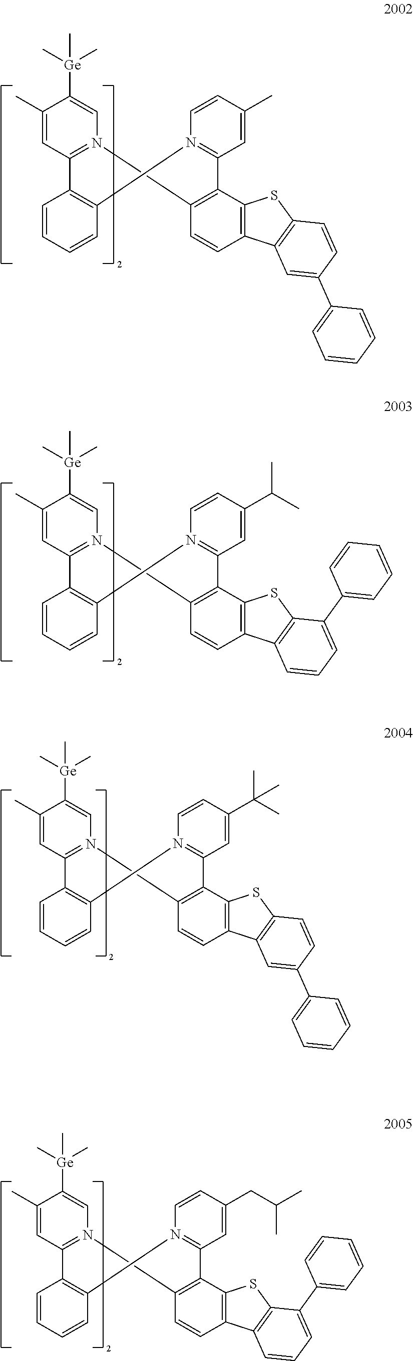

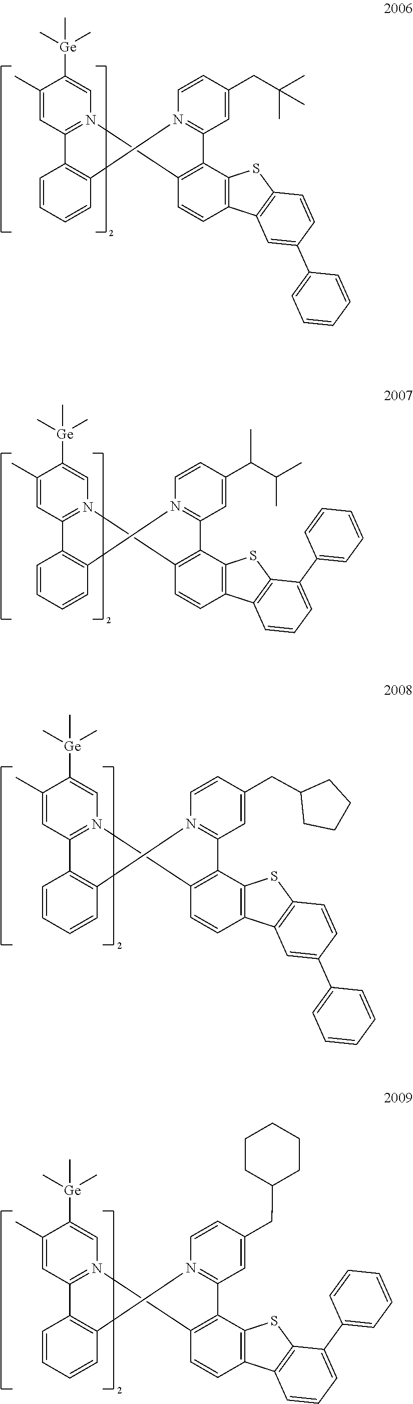

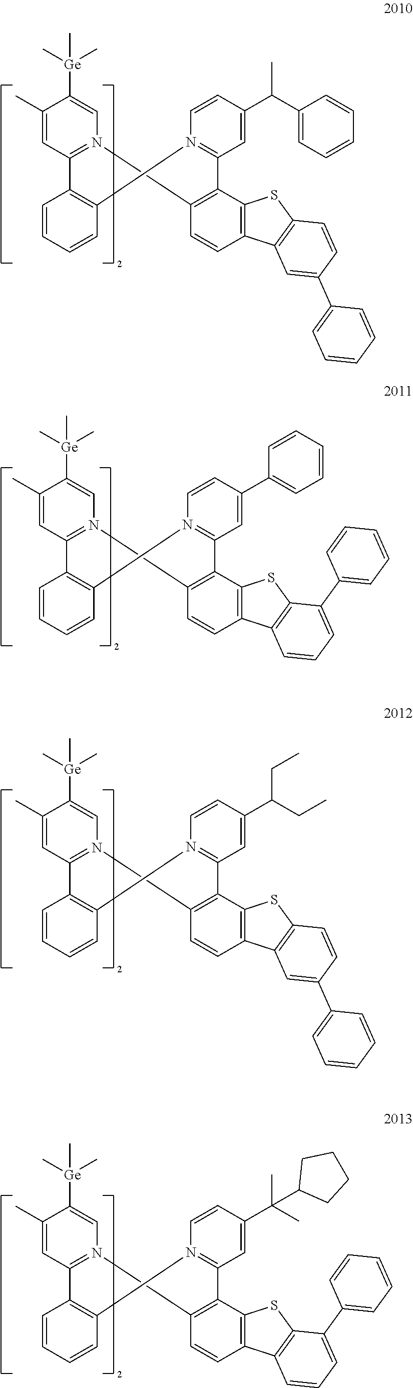

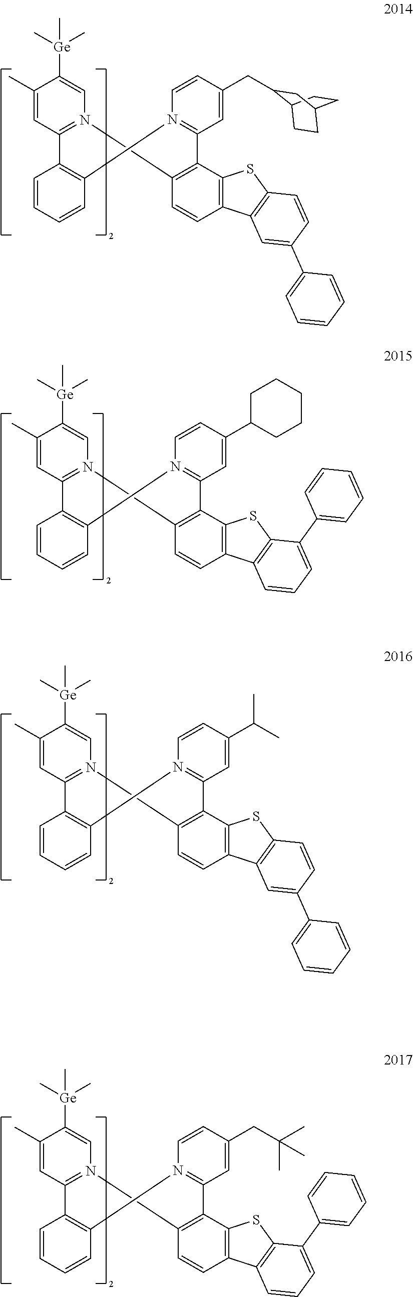

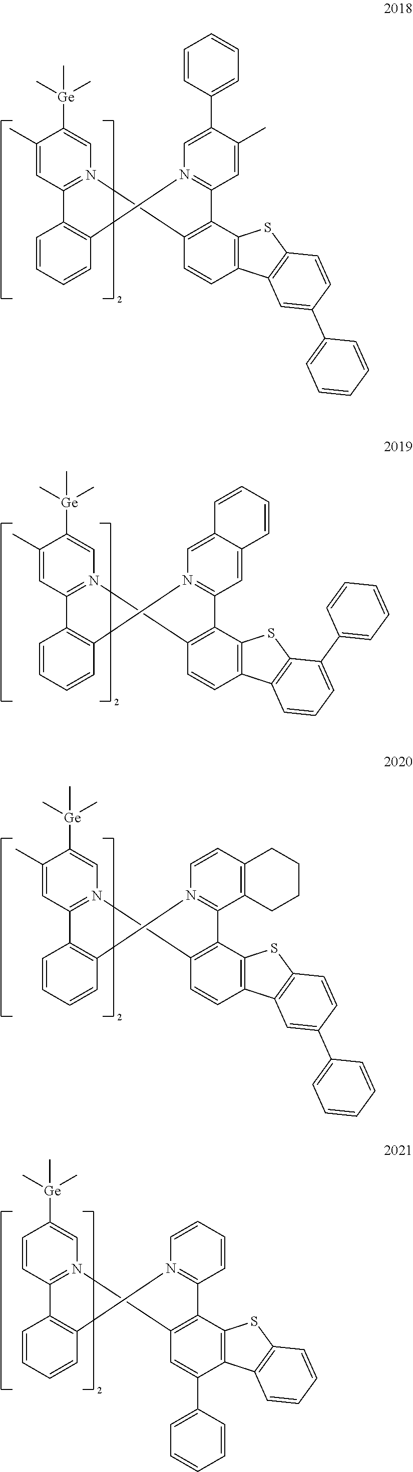

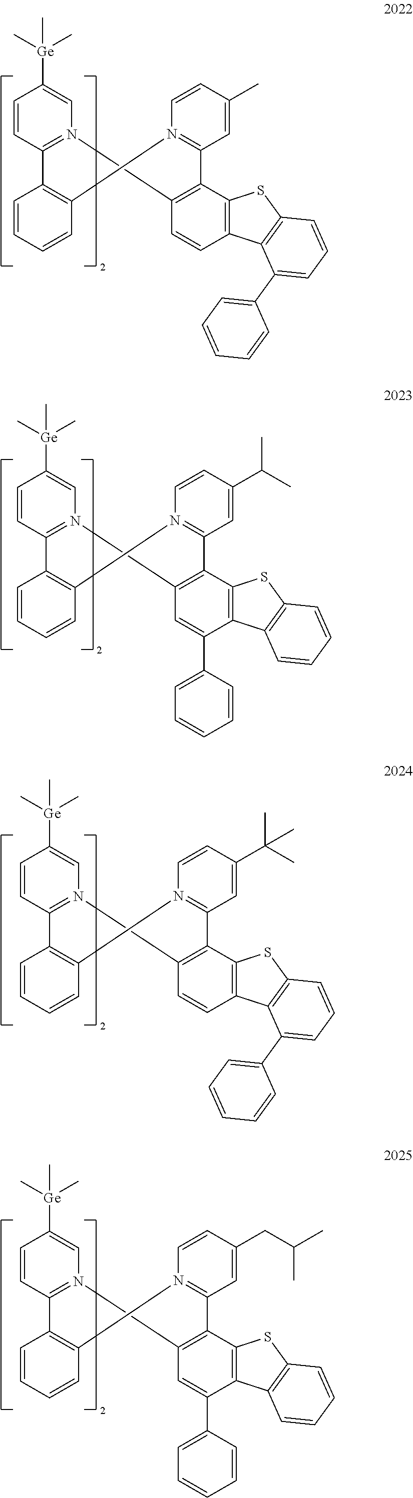

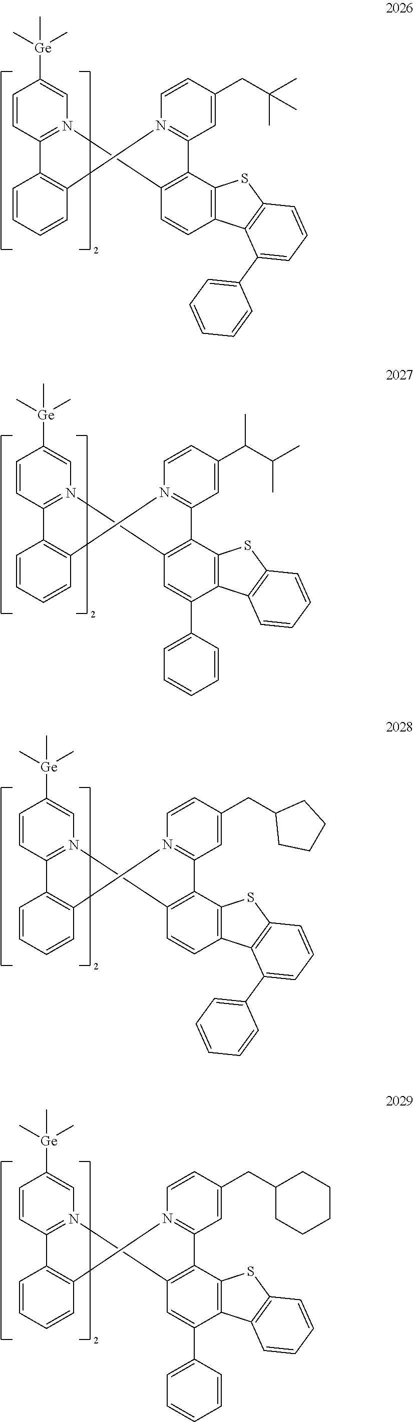

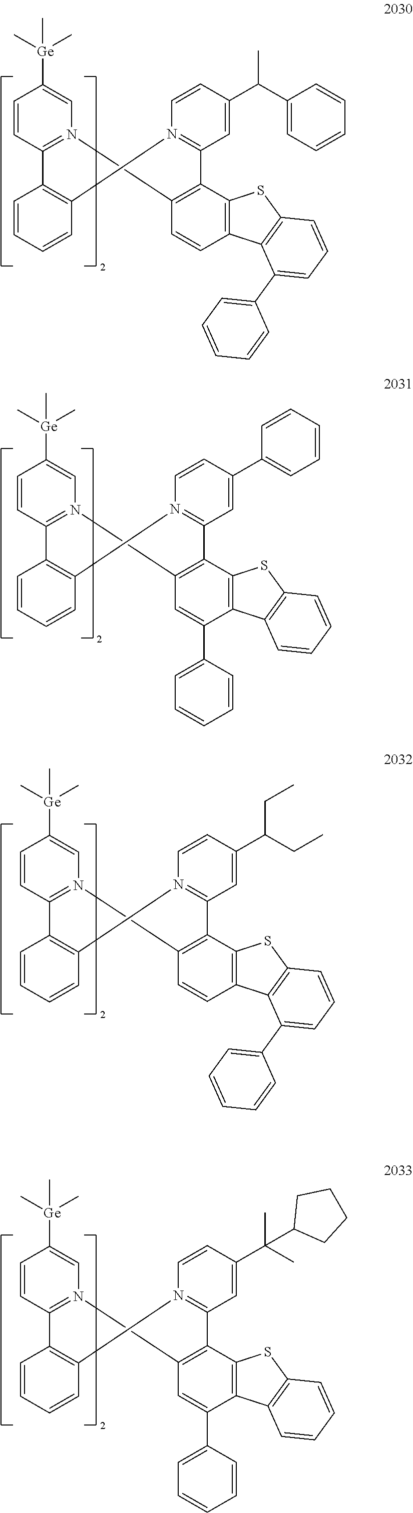

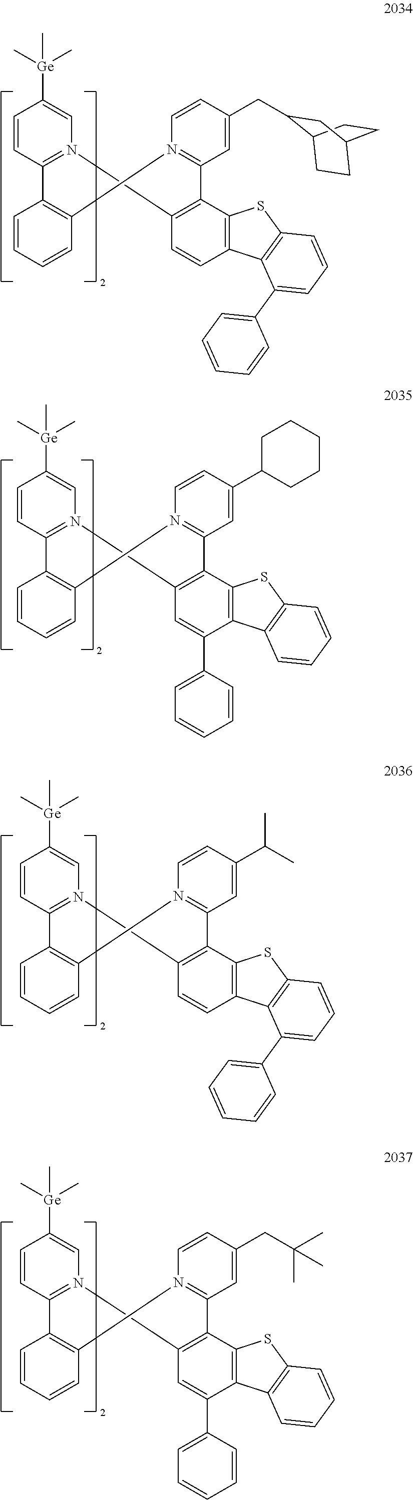

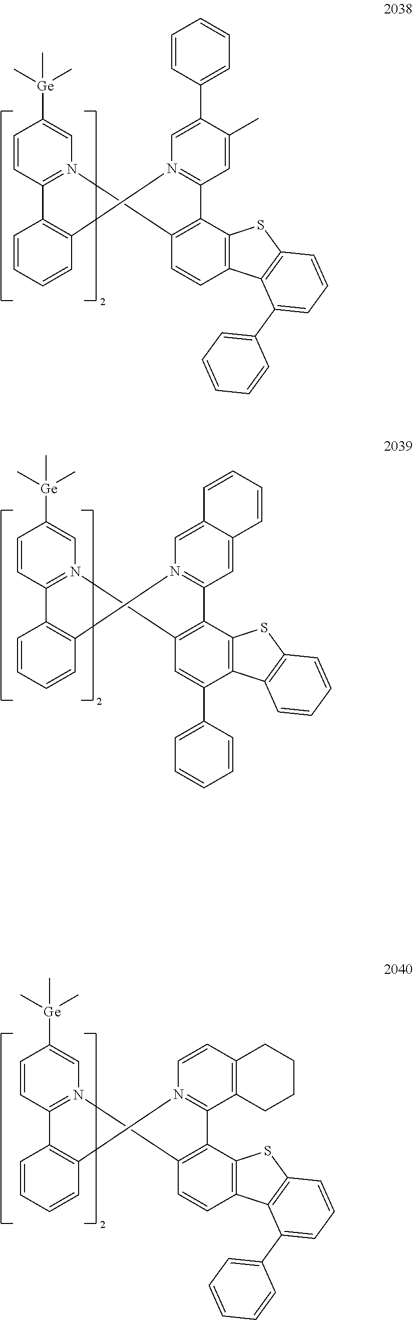

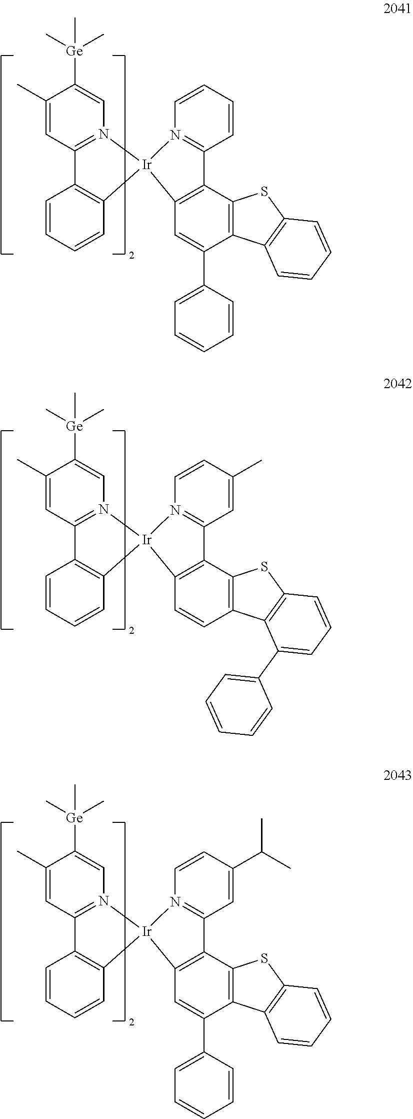

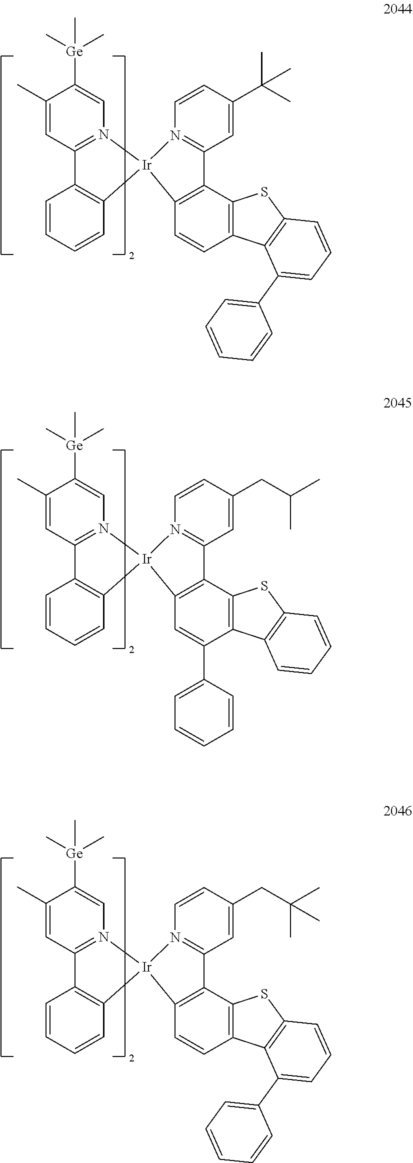

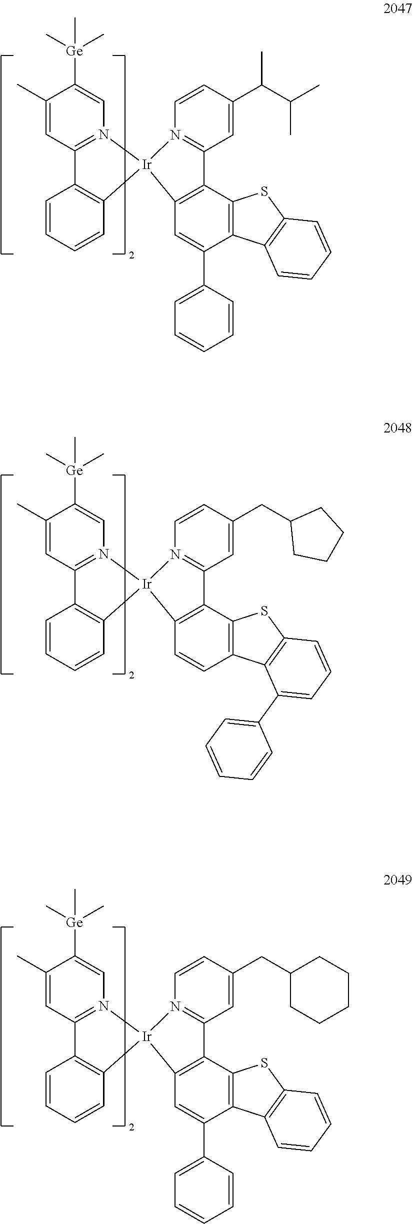

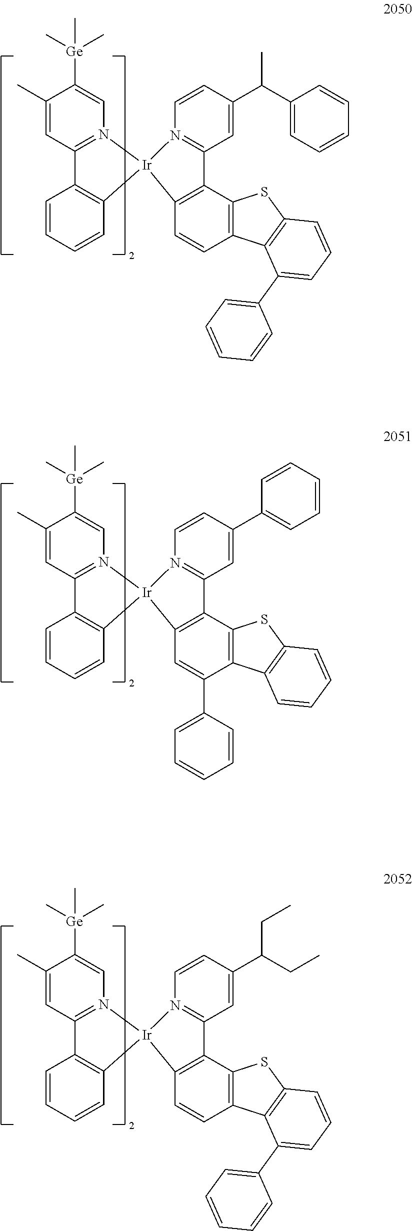

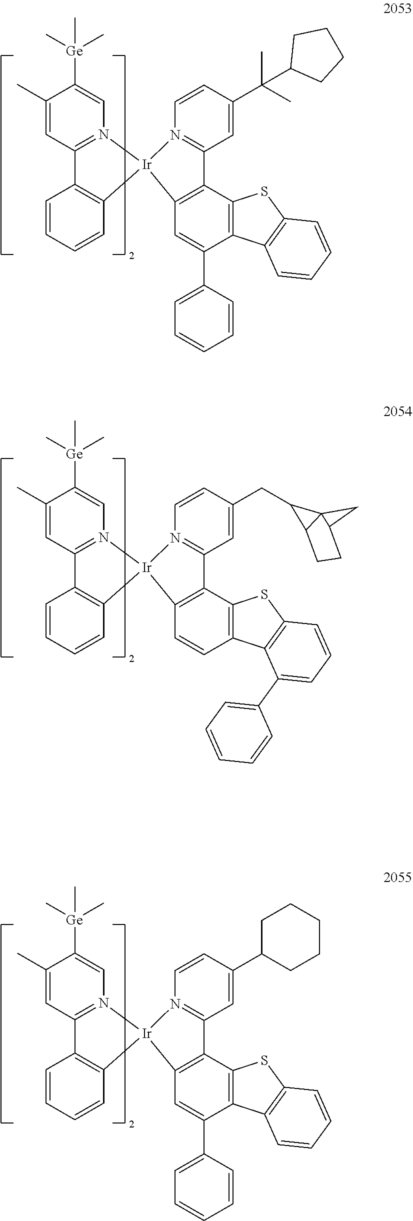

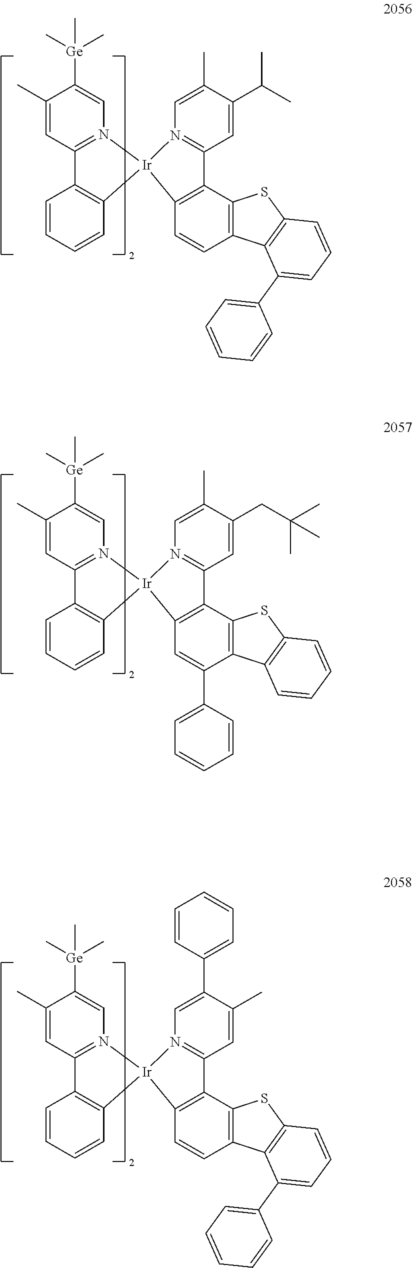

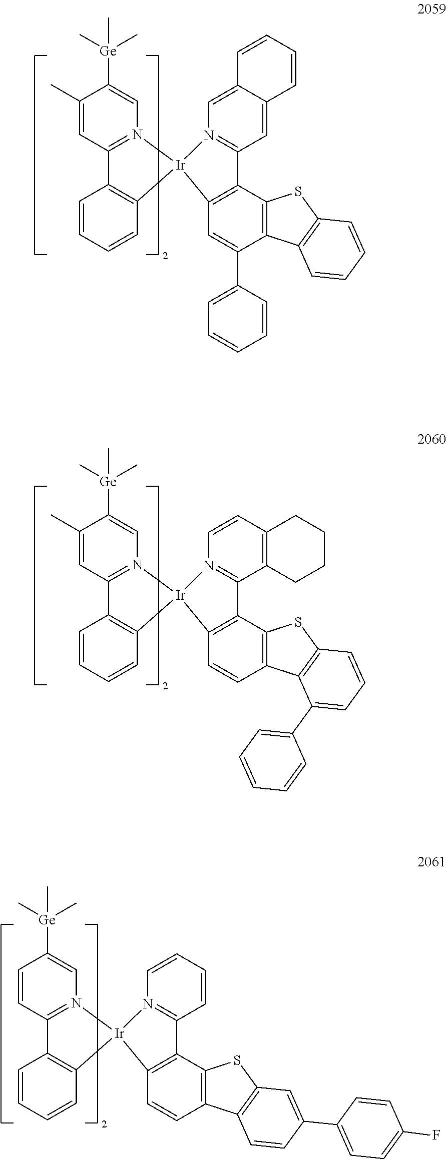

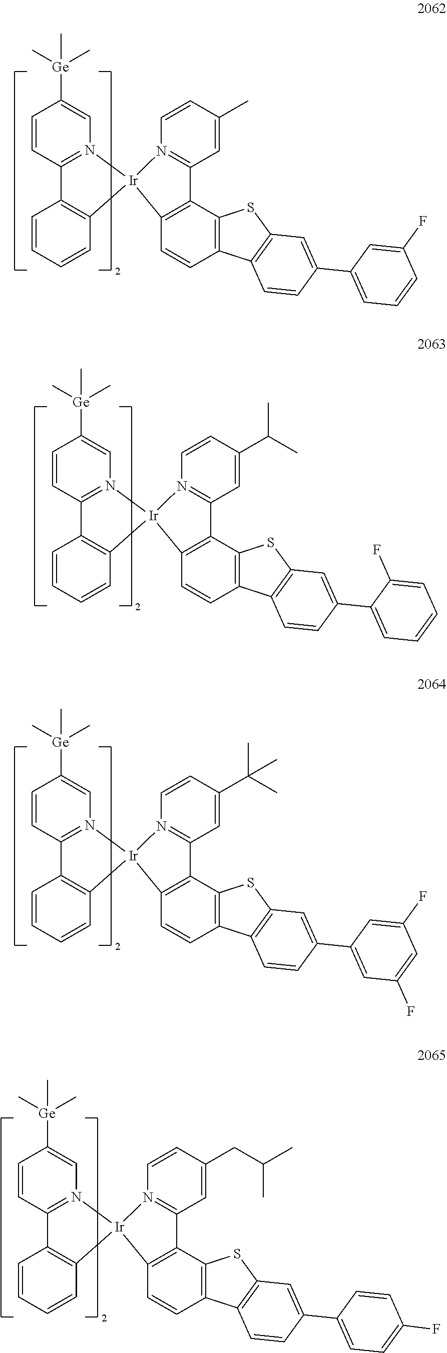

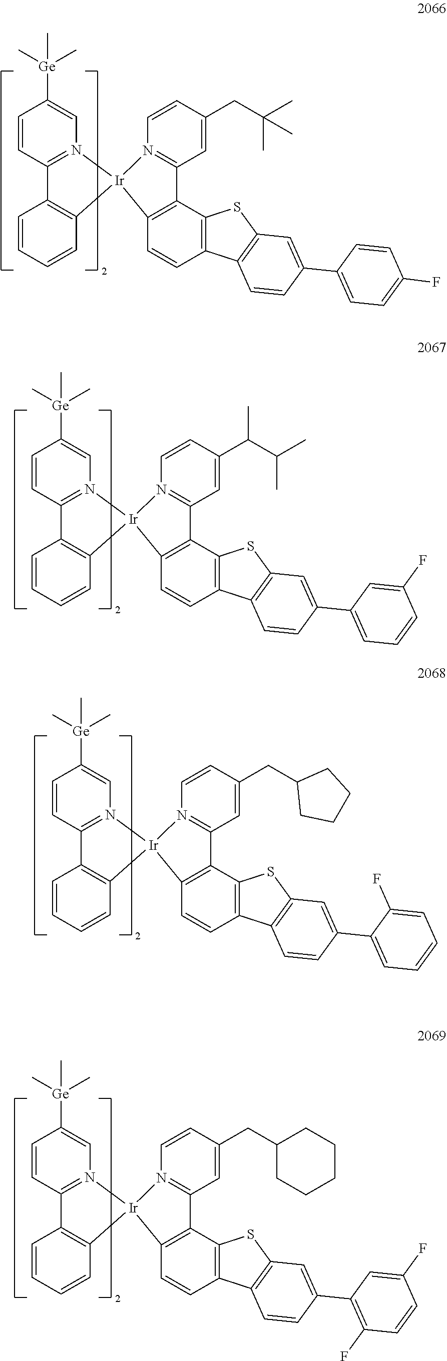

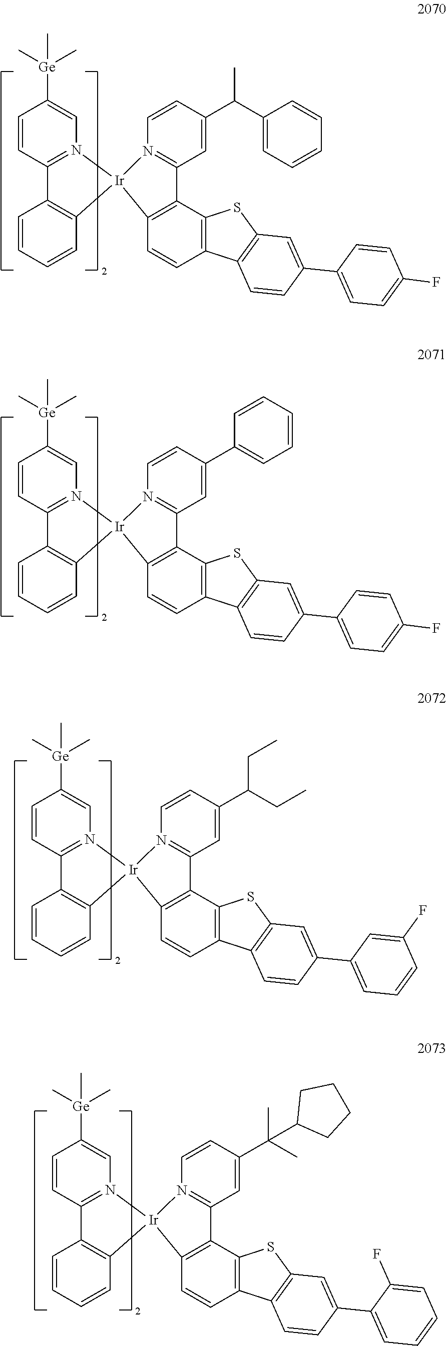

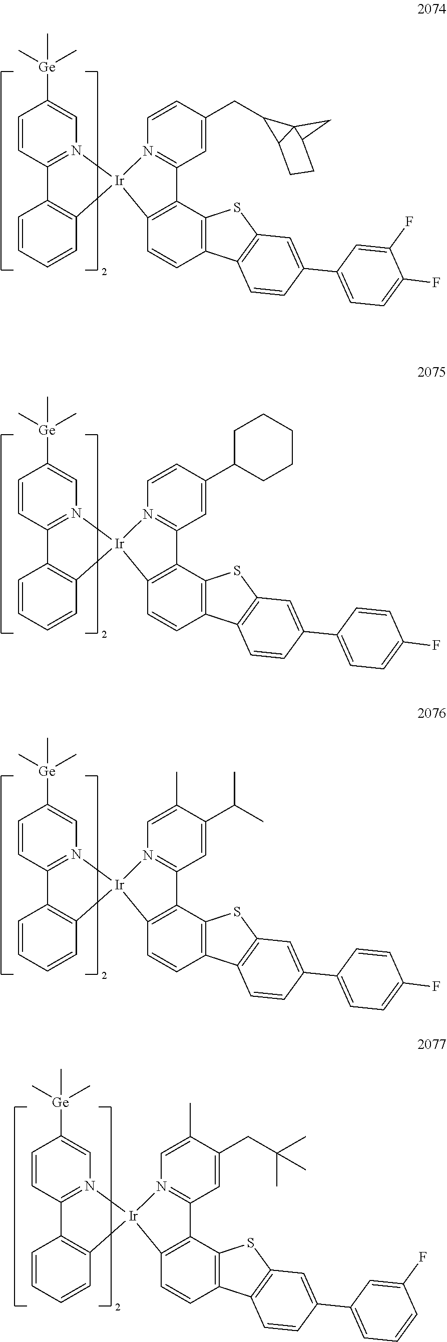

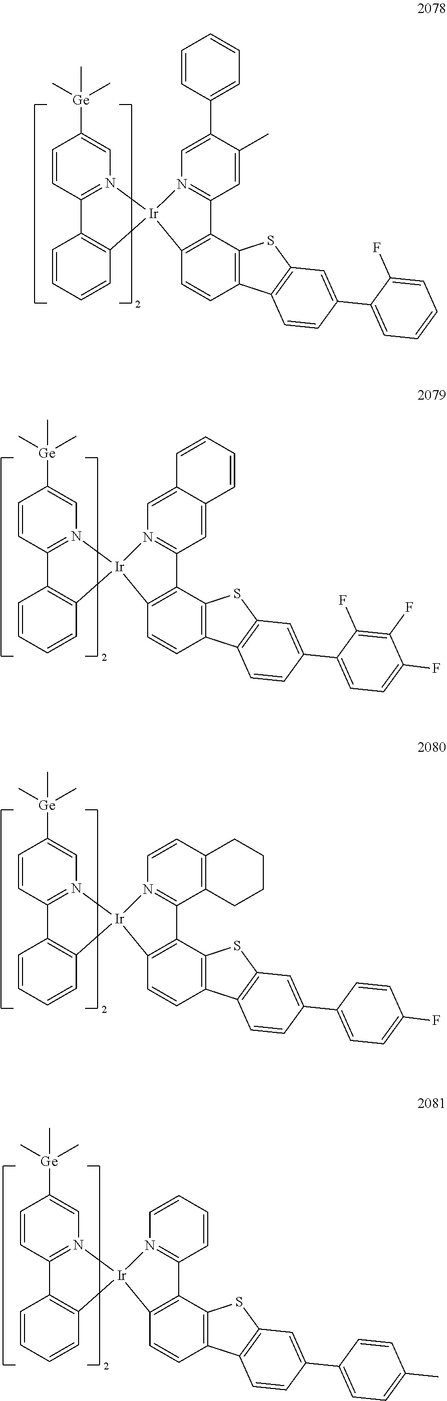

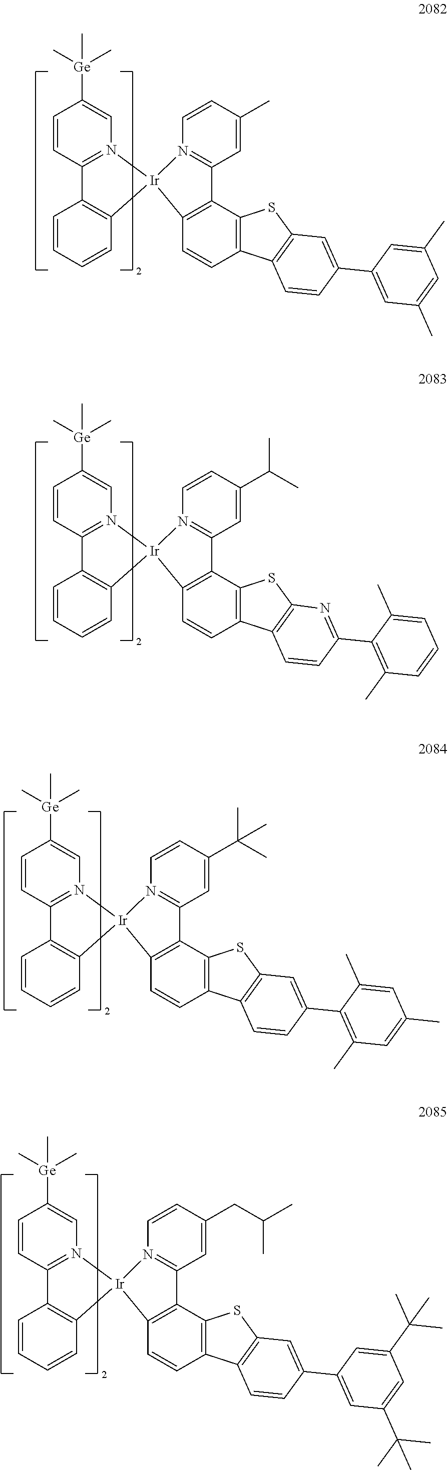

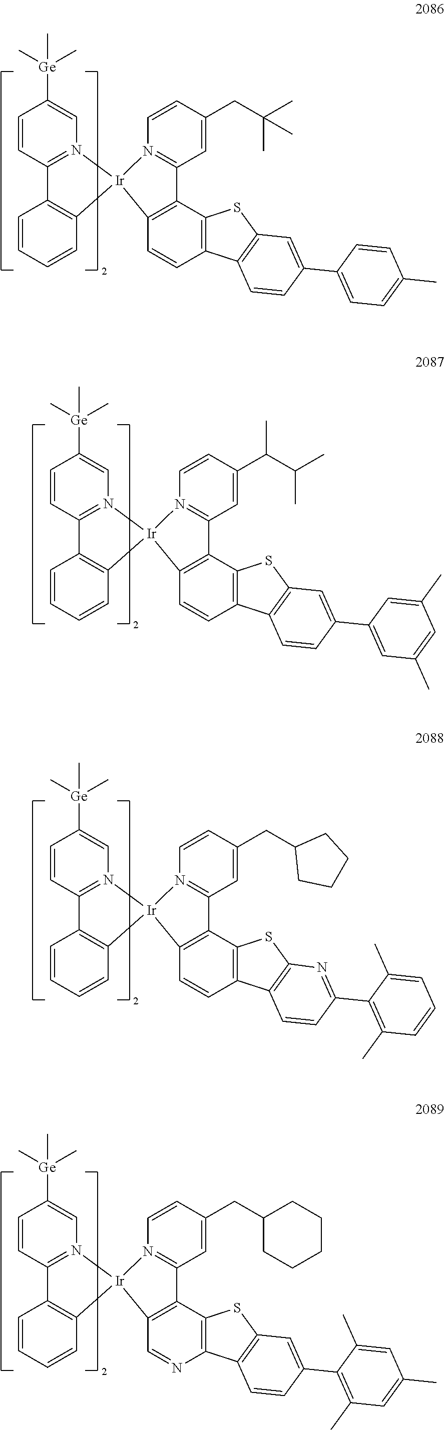

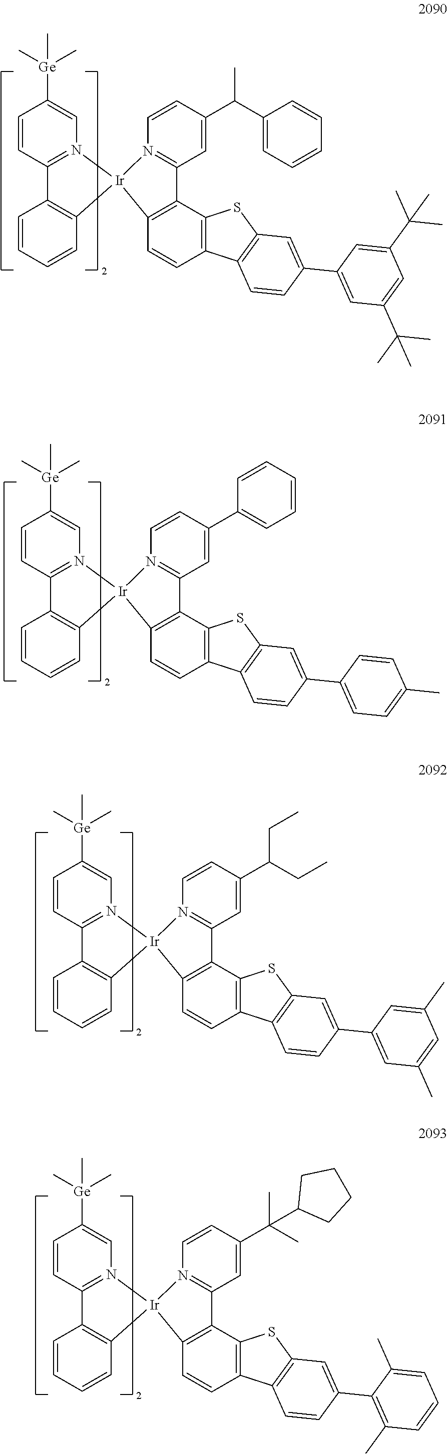

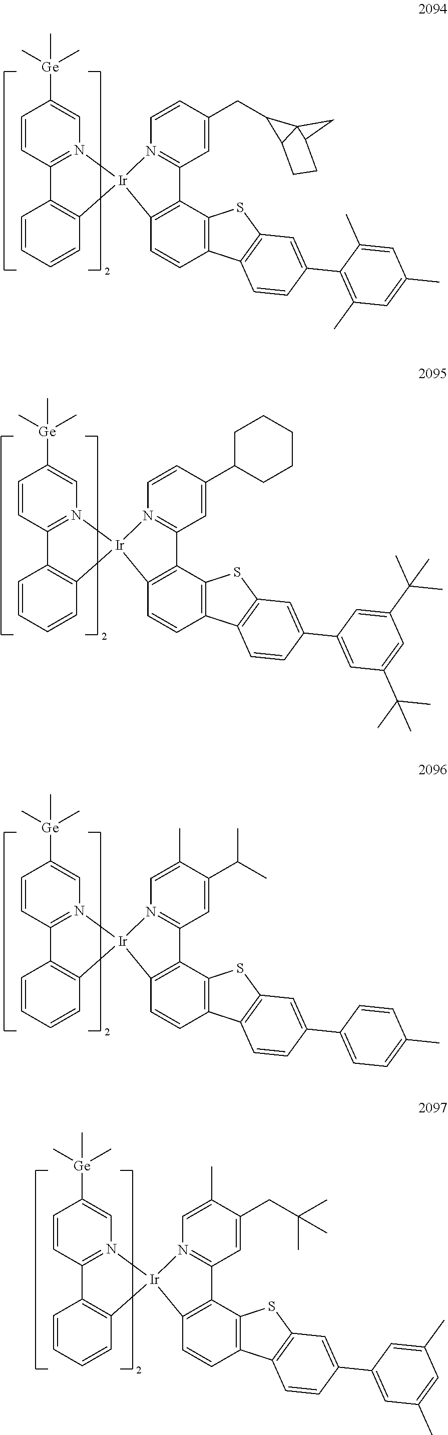

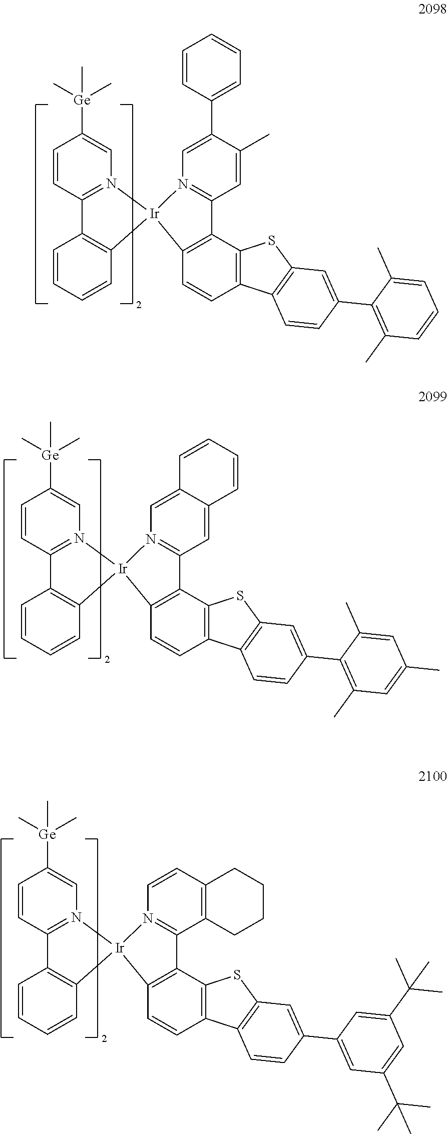

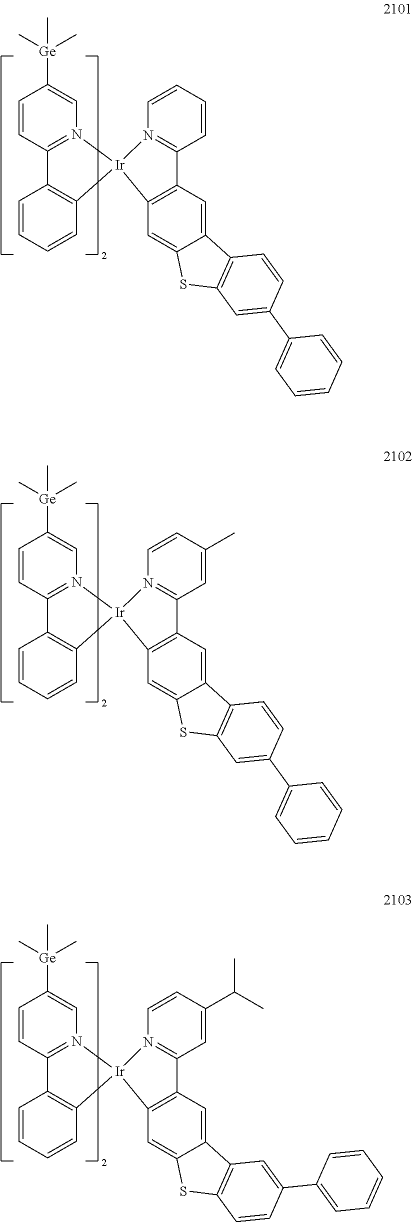

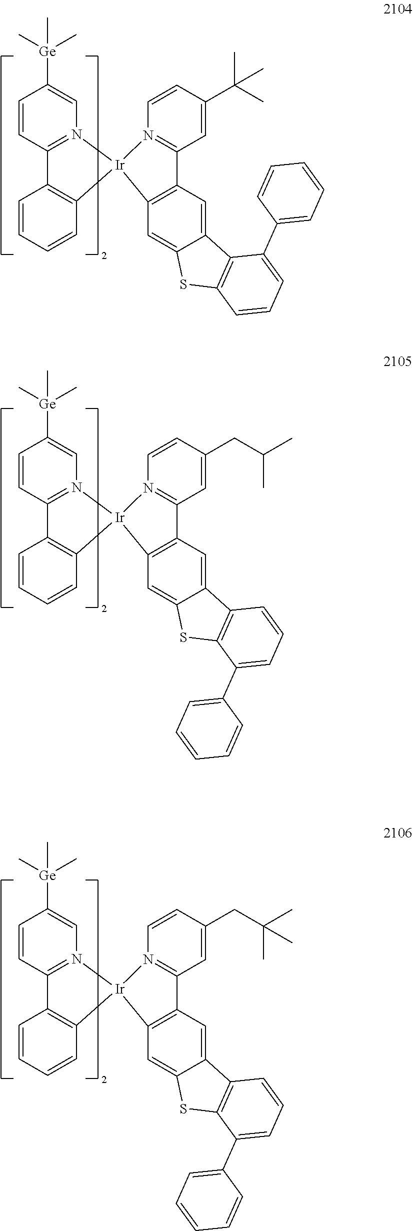

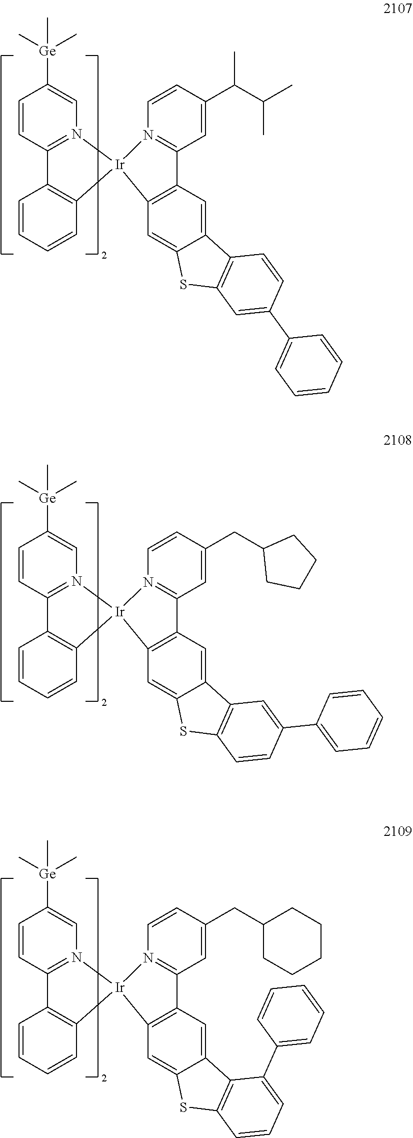

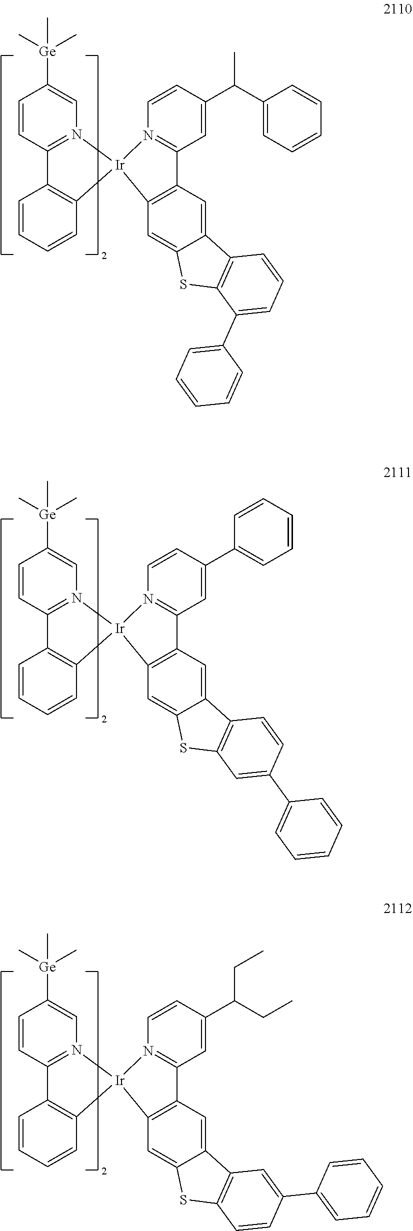

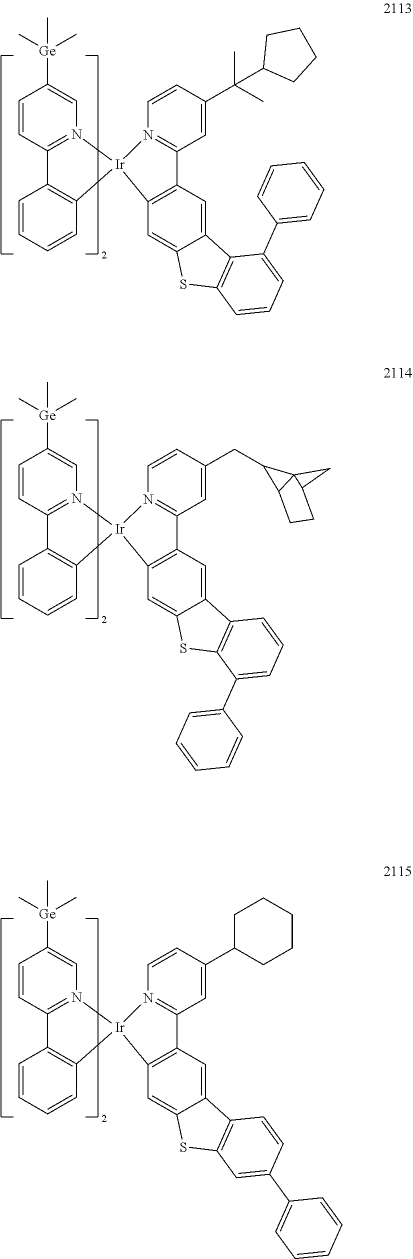

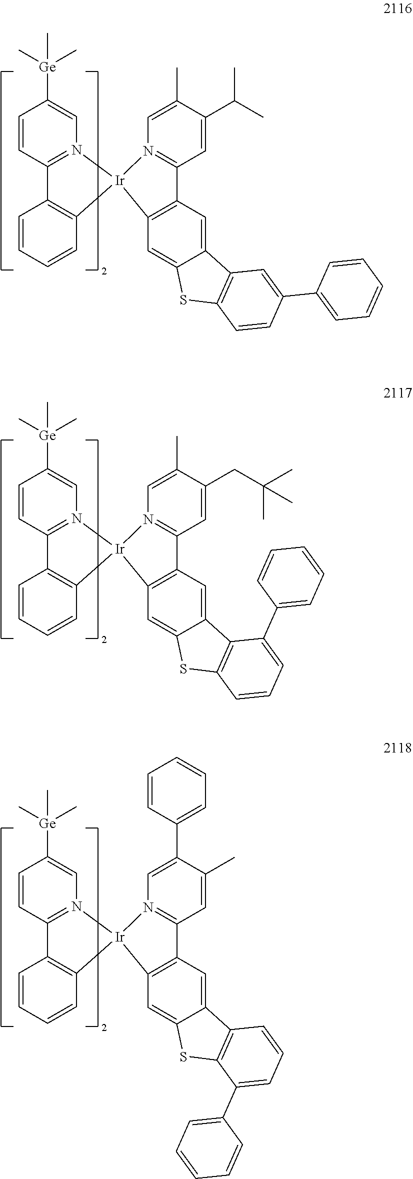

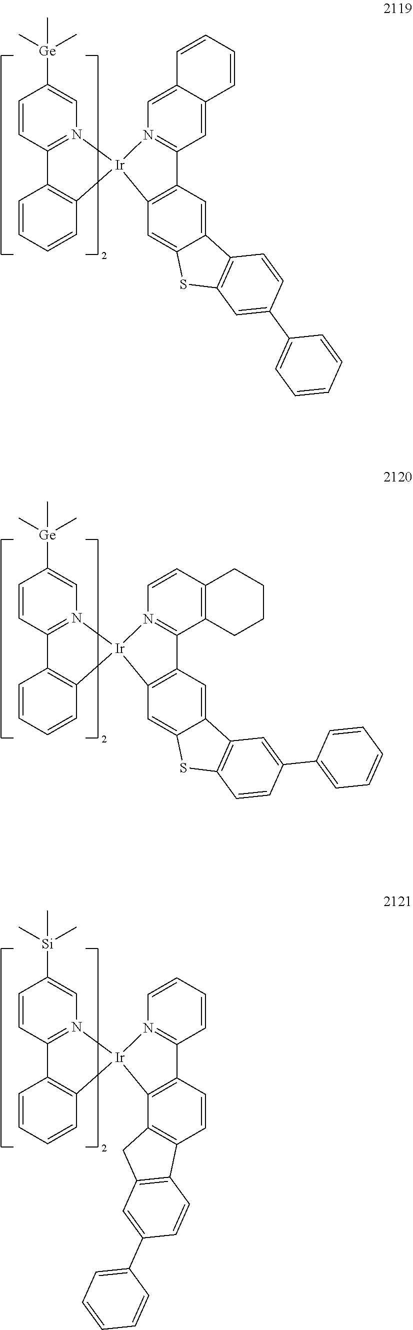

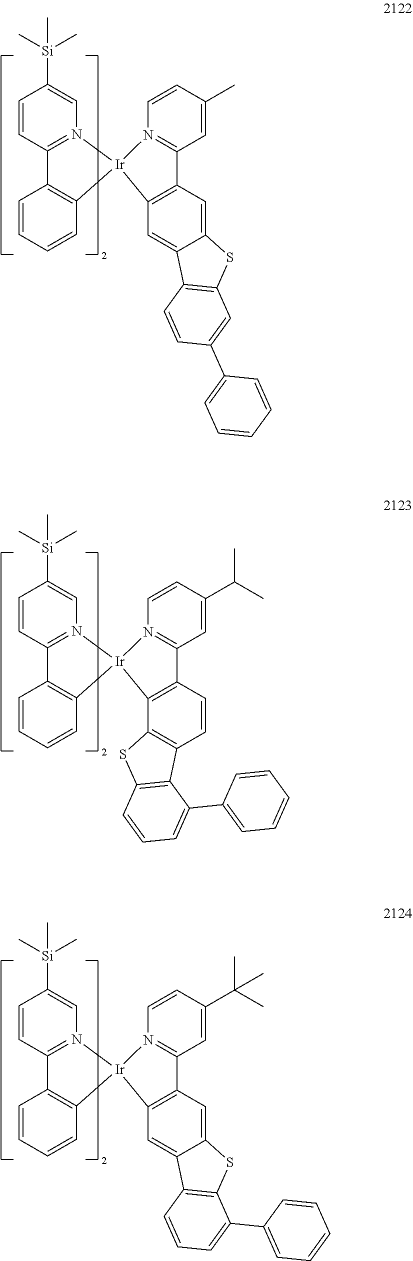

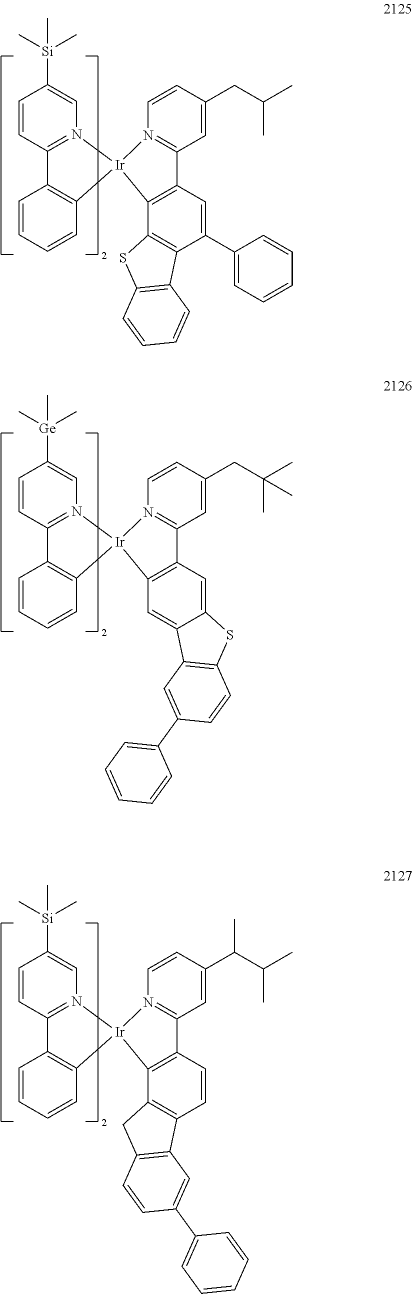

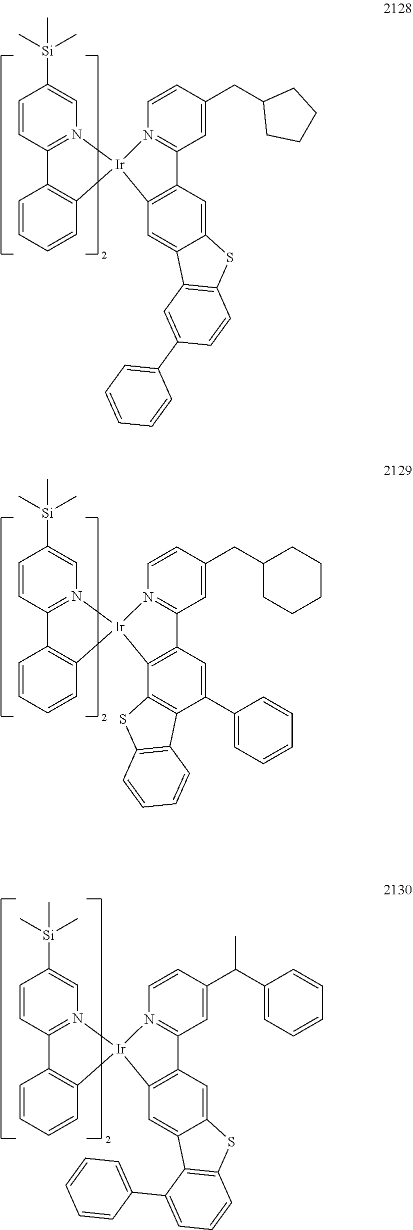

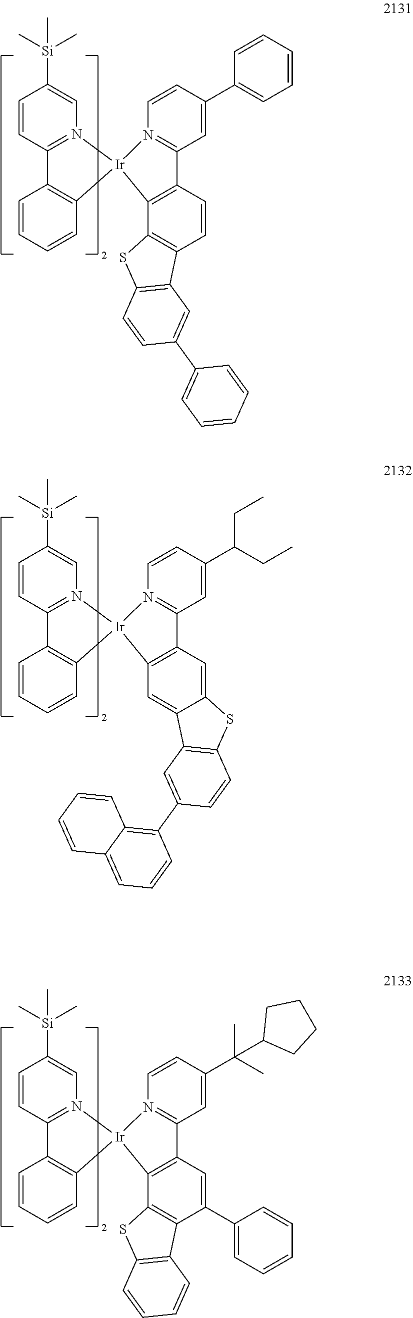

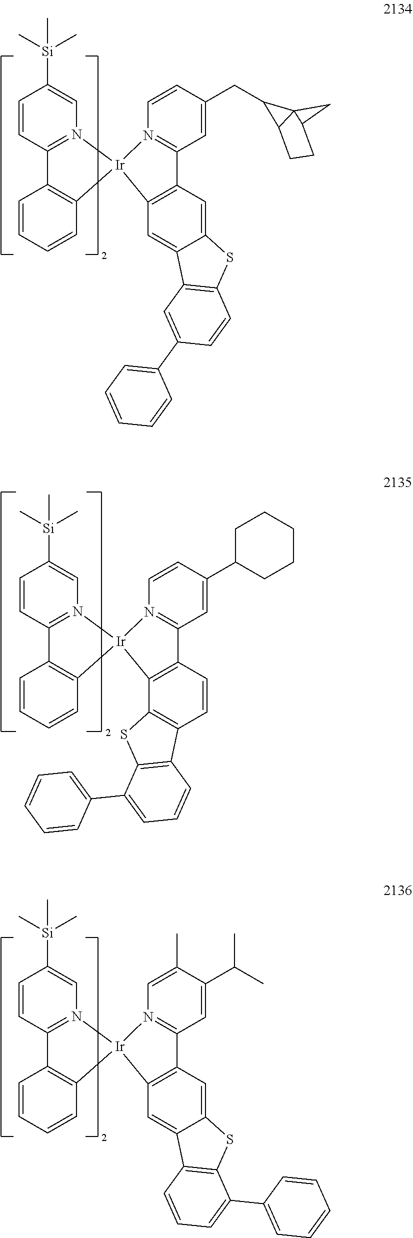

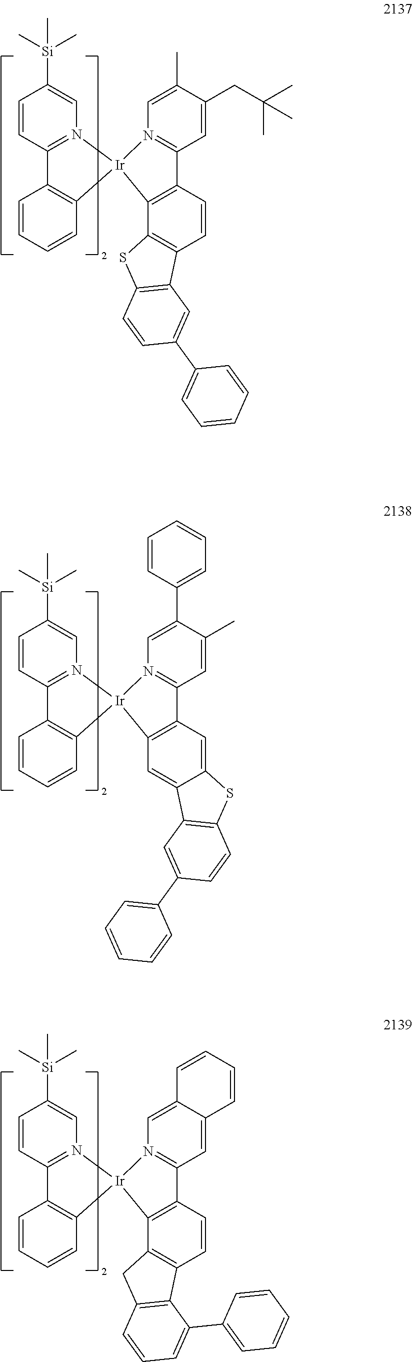

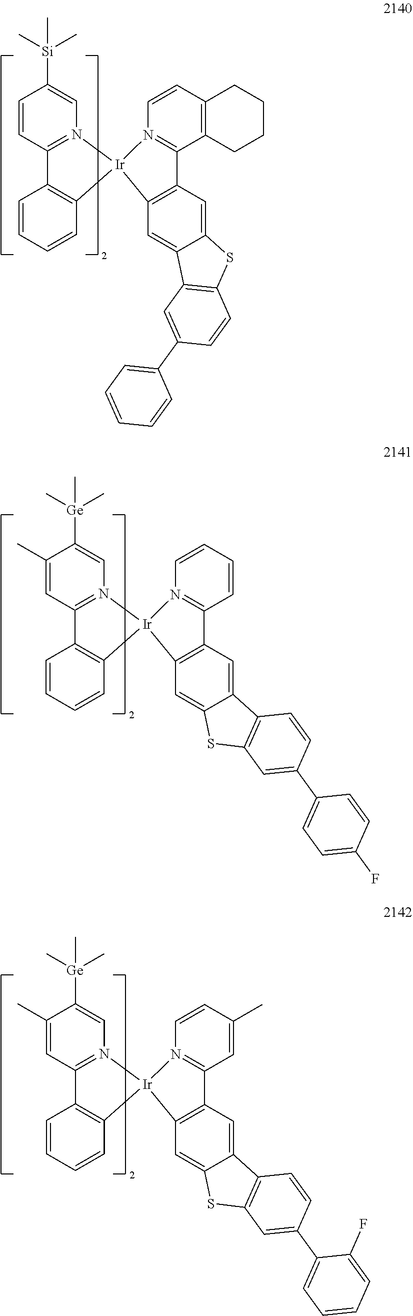

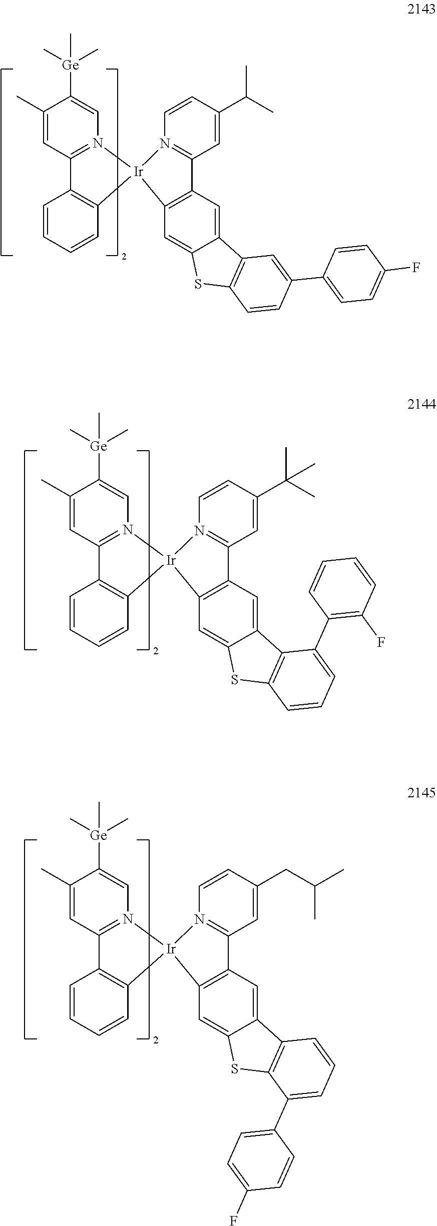

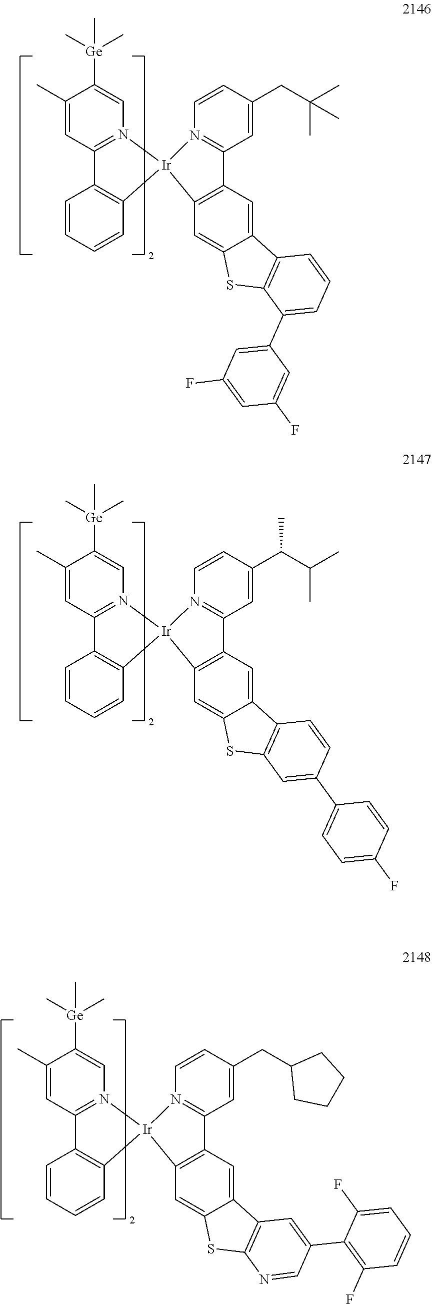

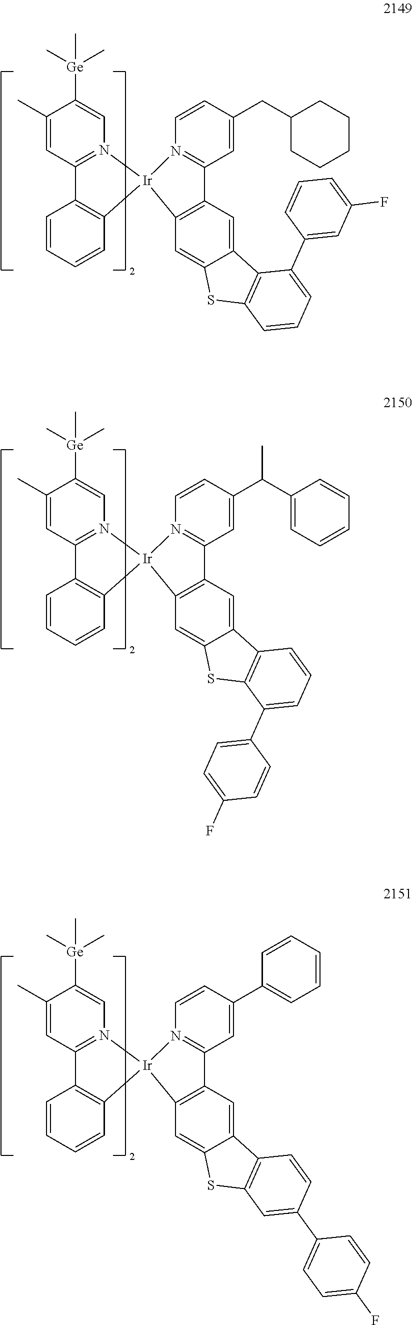

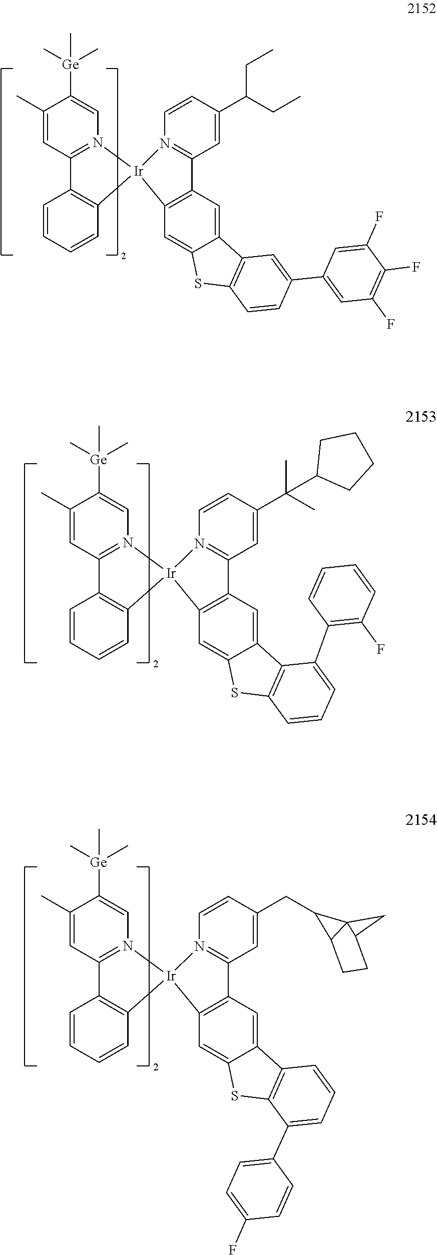

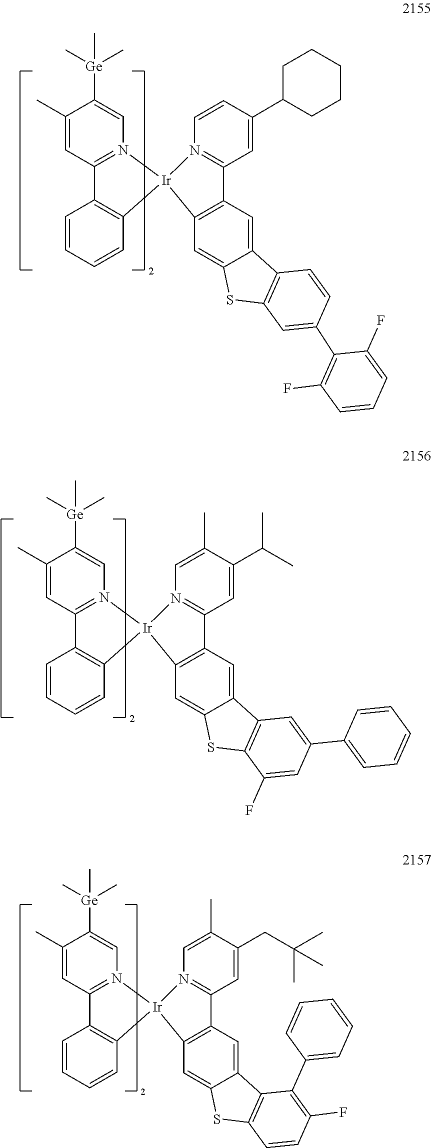

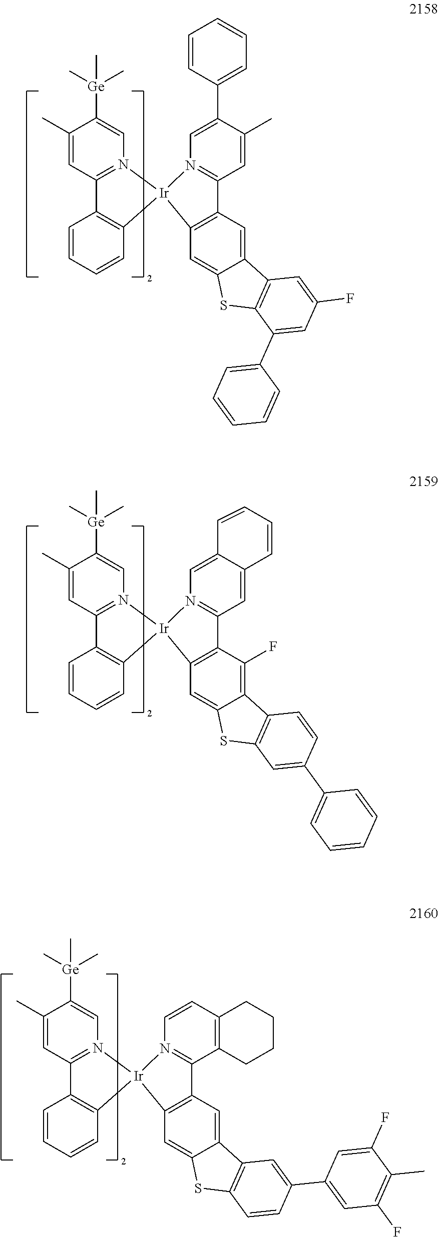

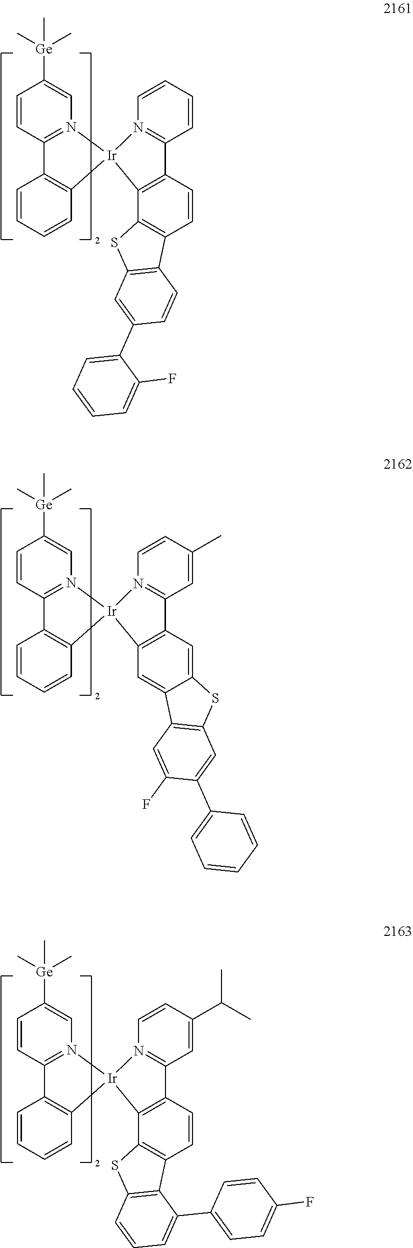

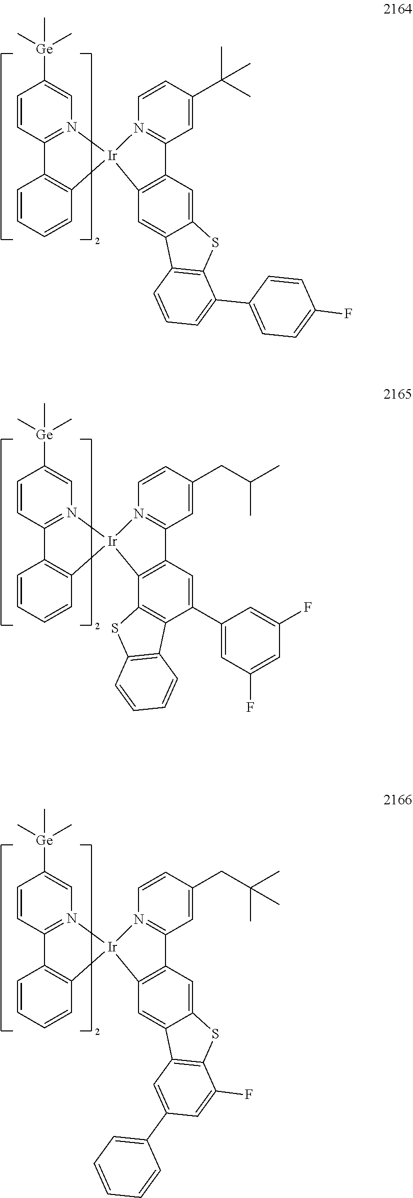

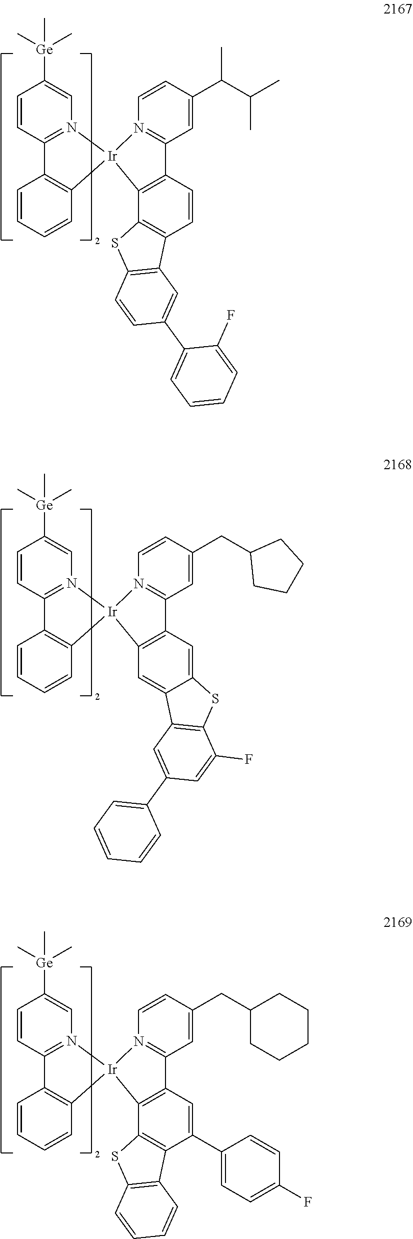

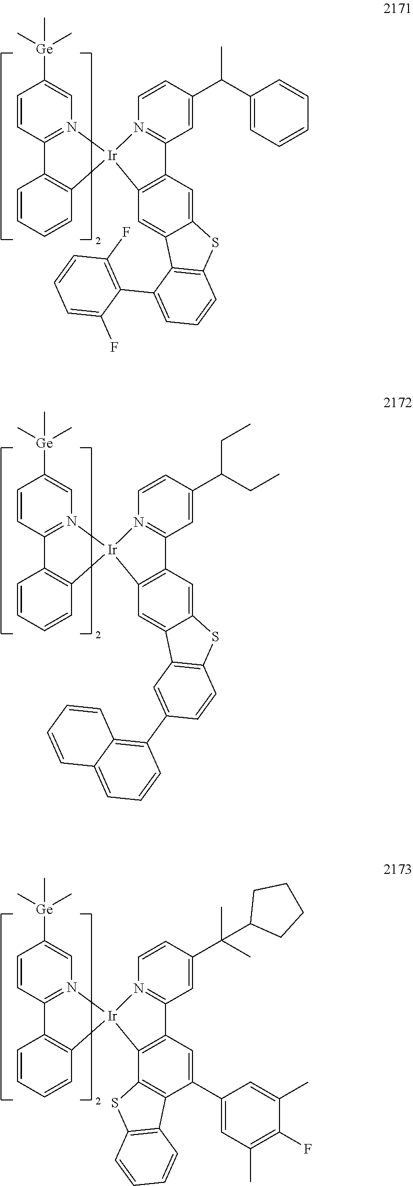

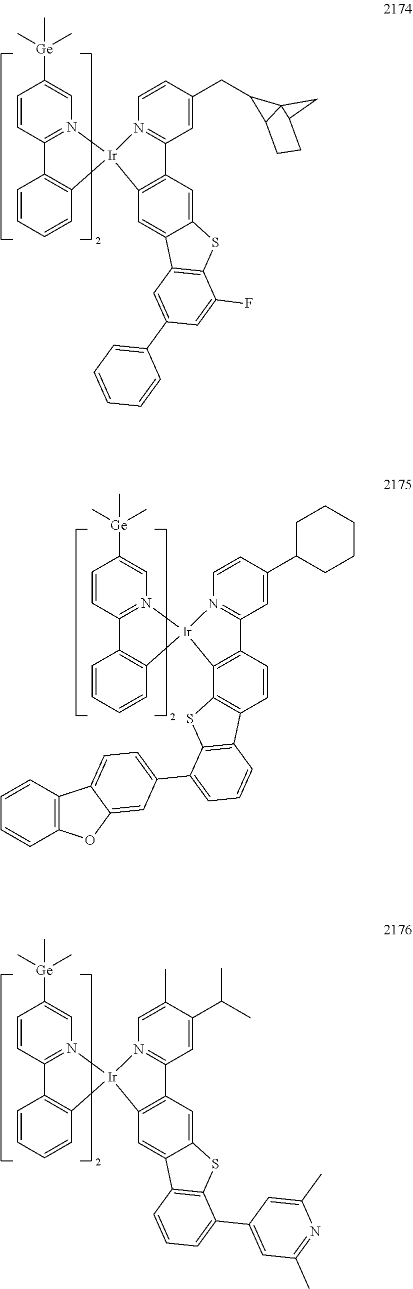

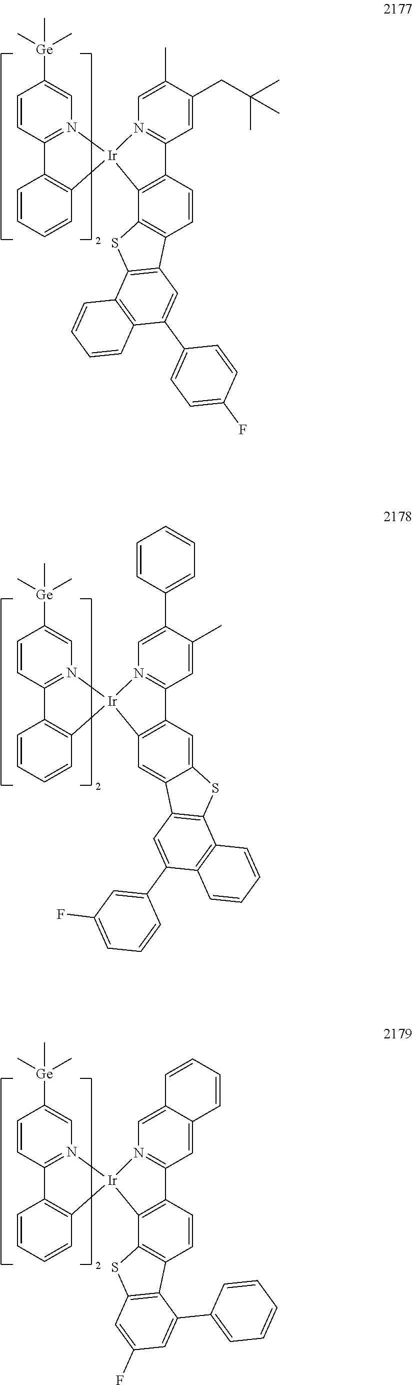

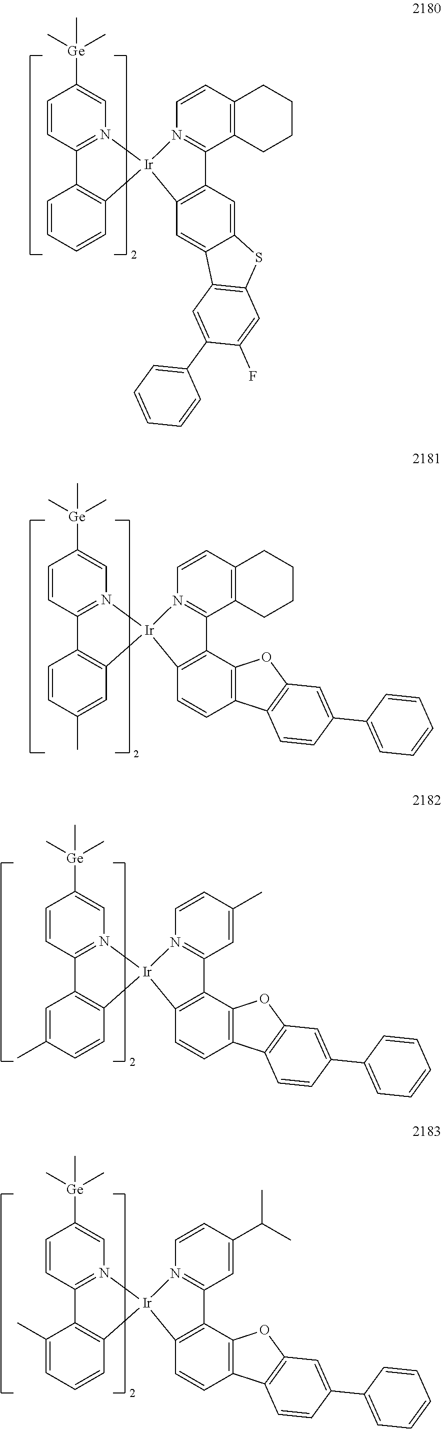

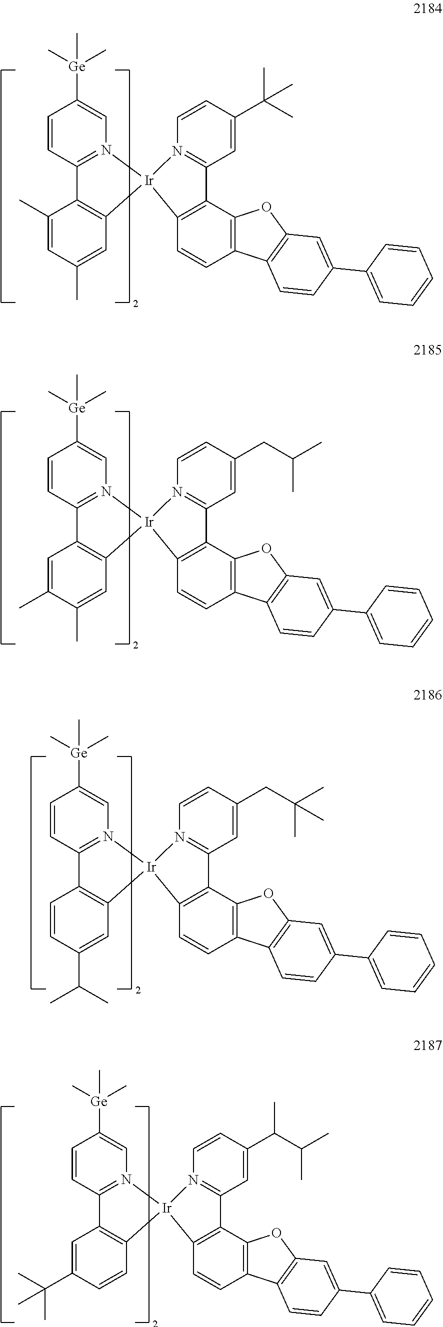

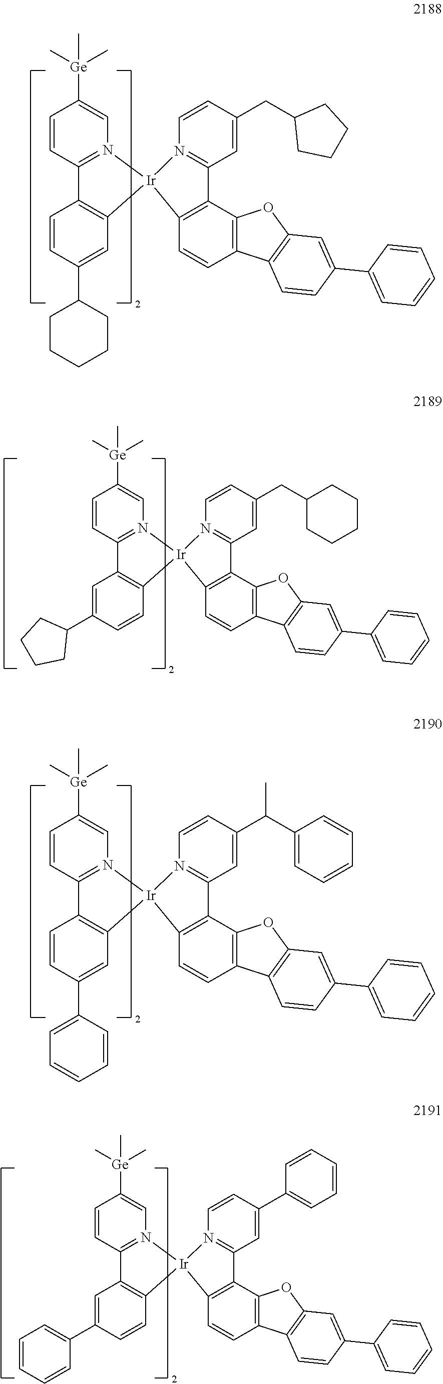

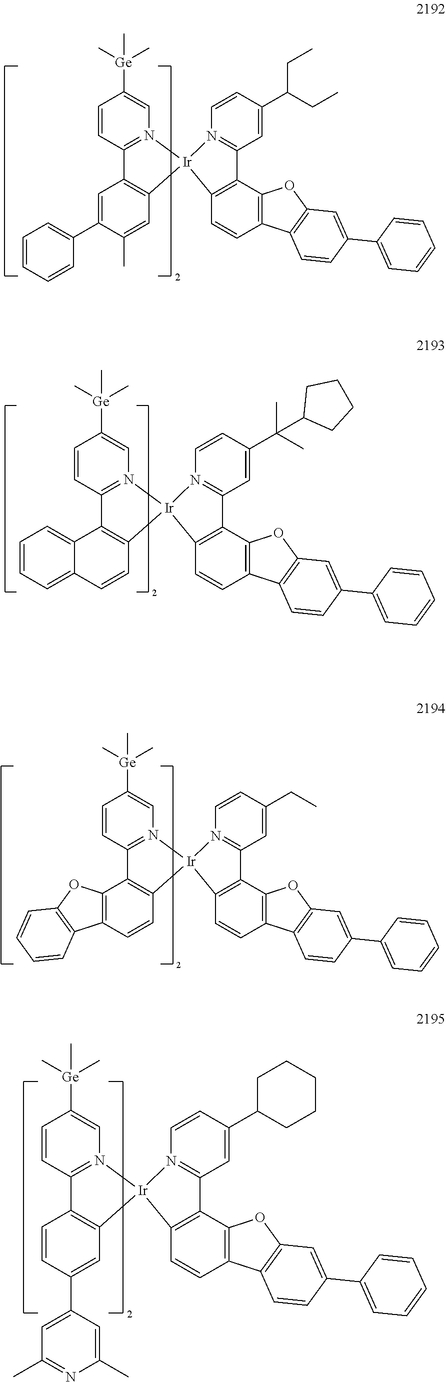

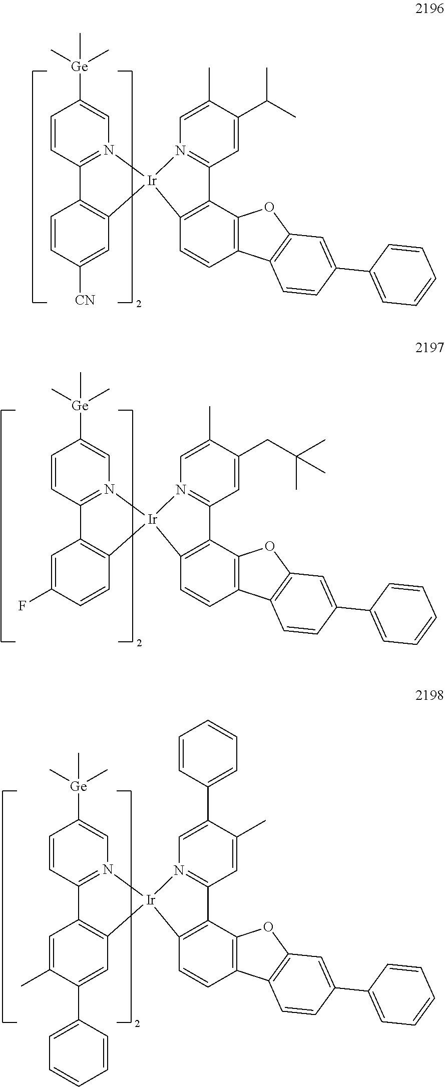

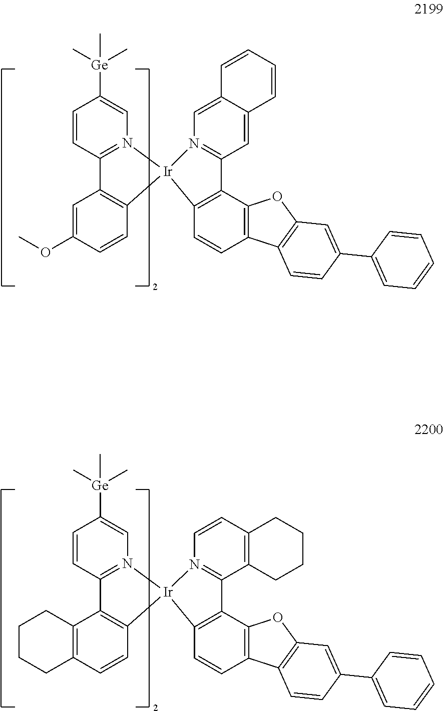

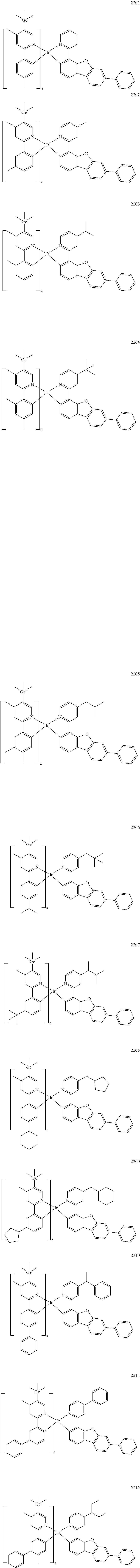

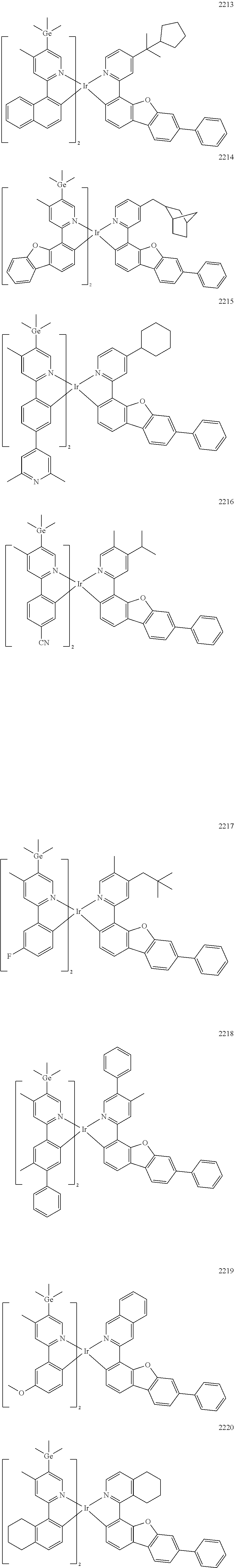

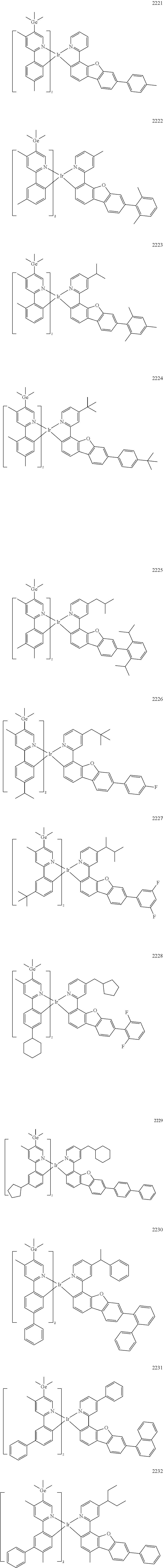

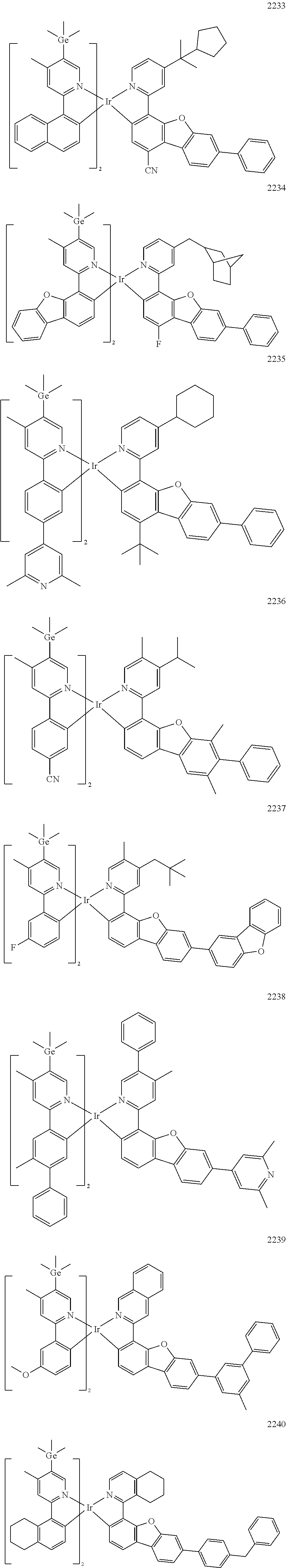

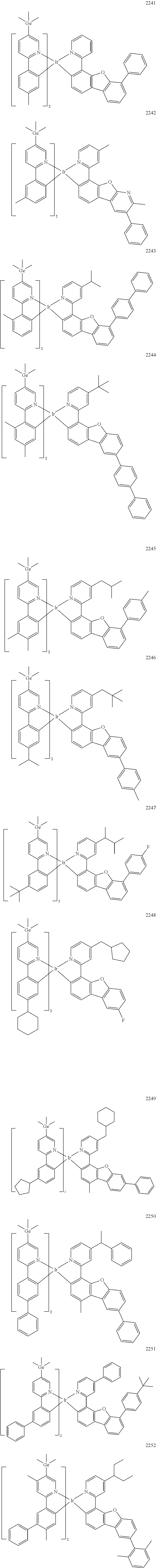

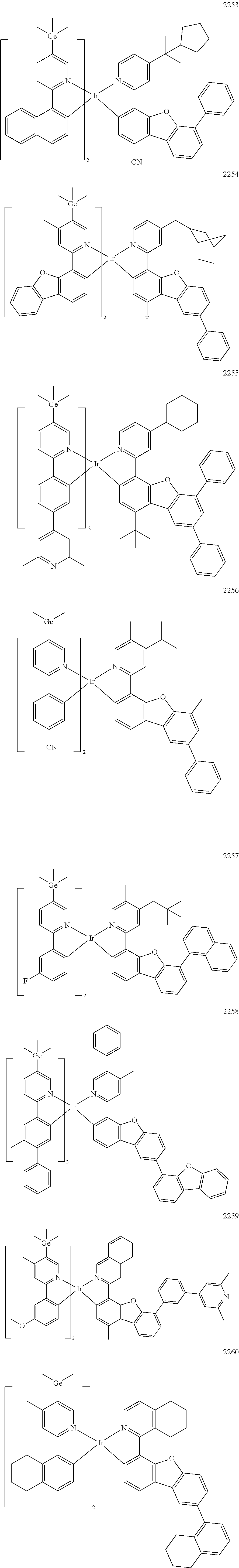

[chemical structure]

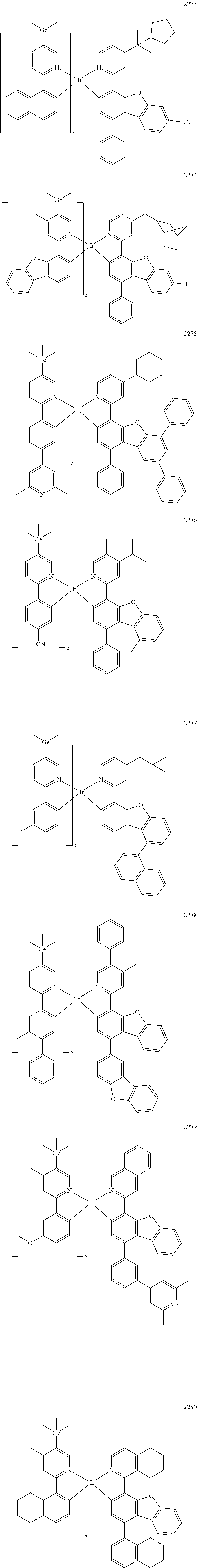

[chemical structure]

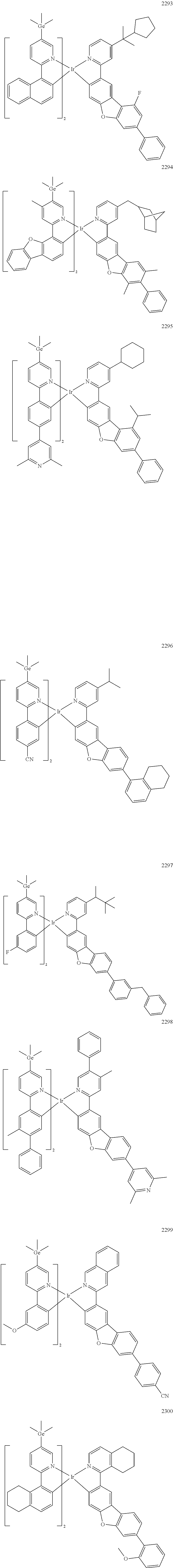

[chemical structure]

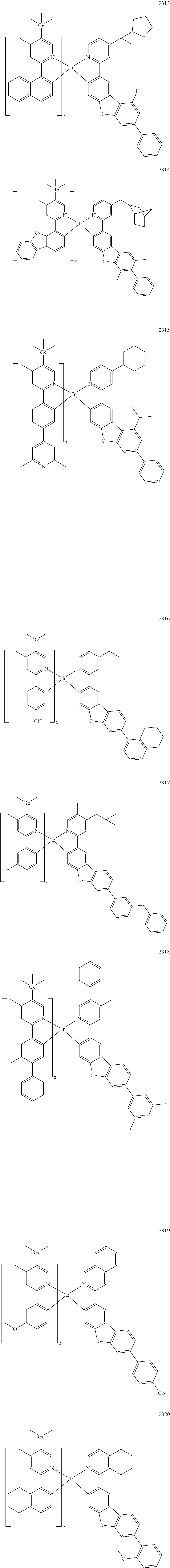

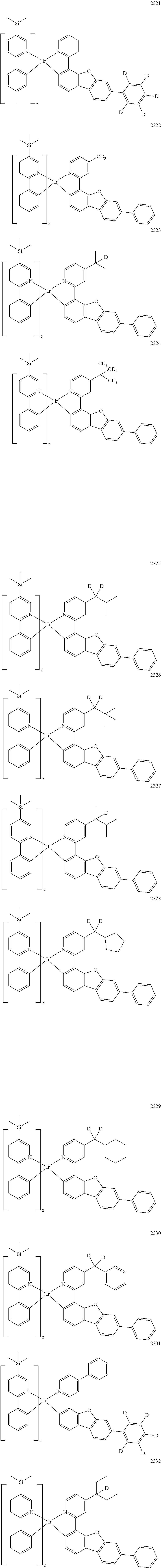

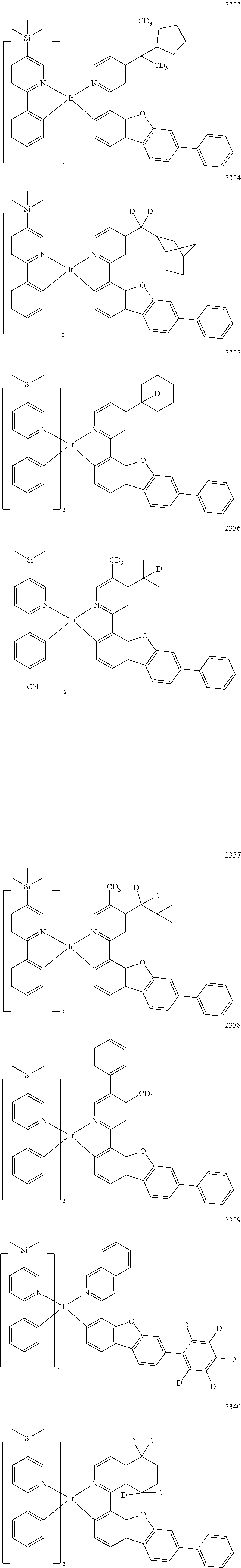

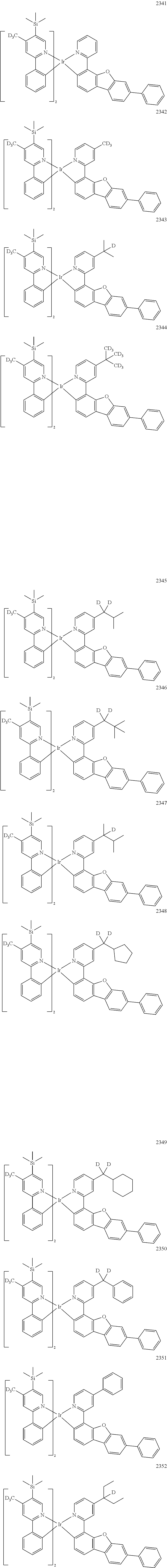

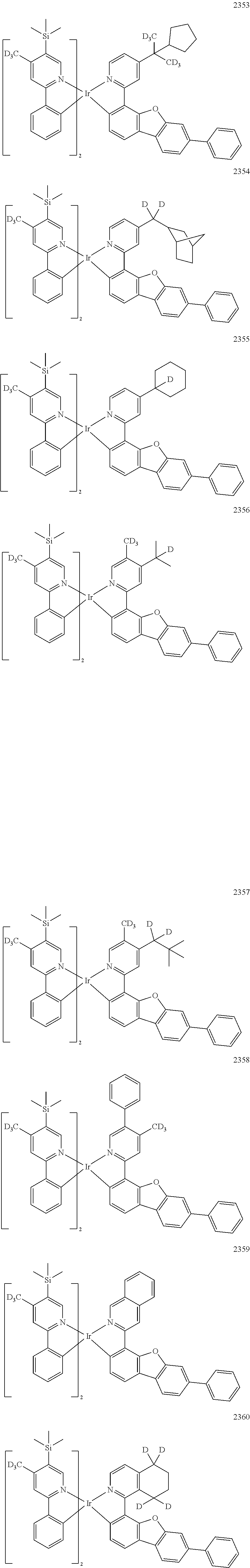

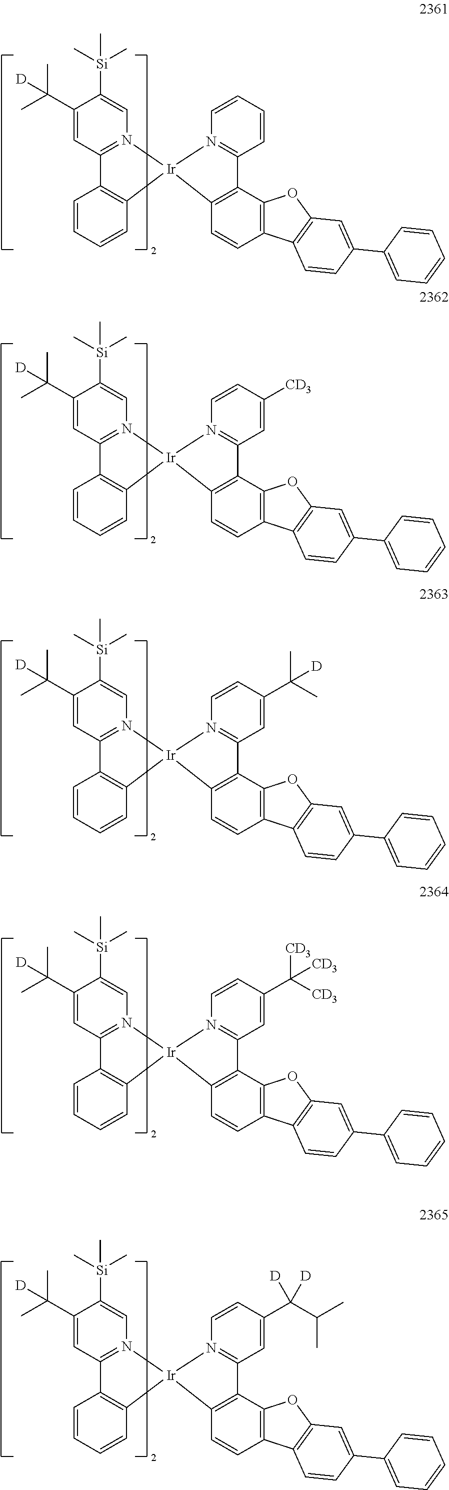

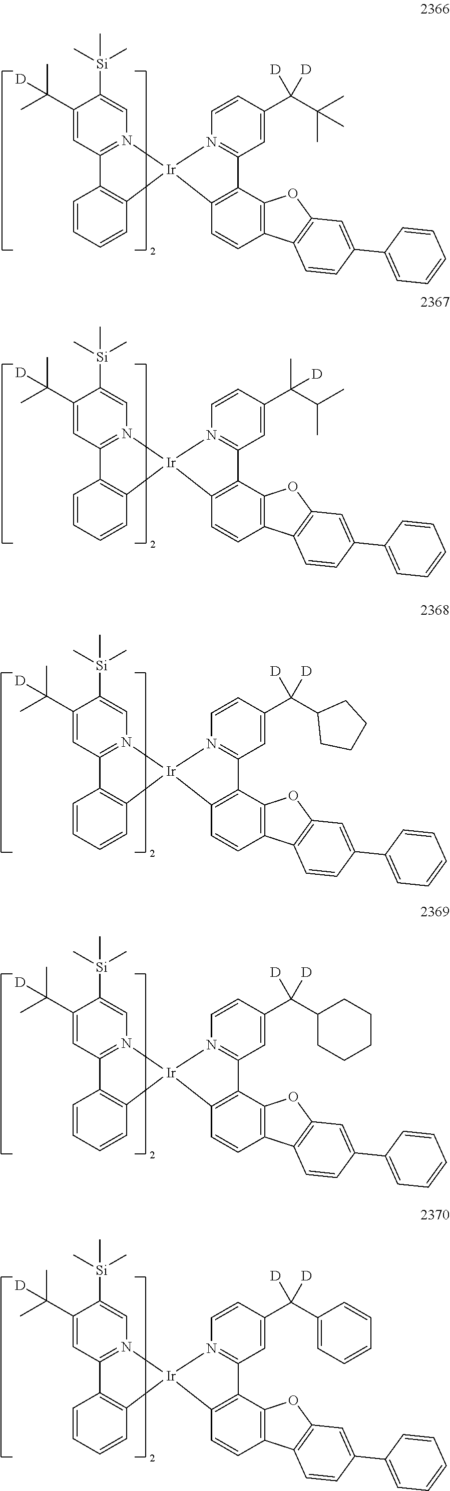

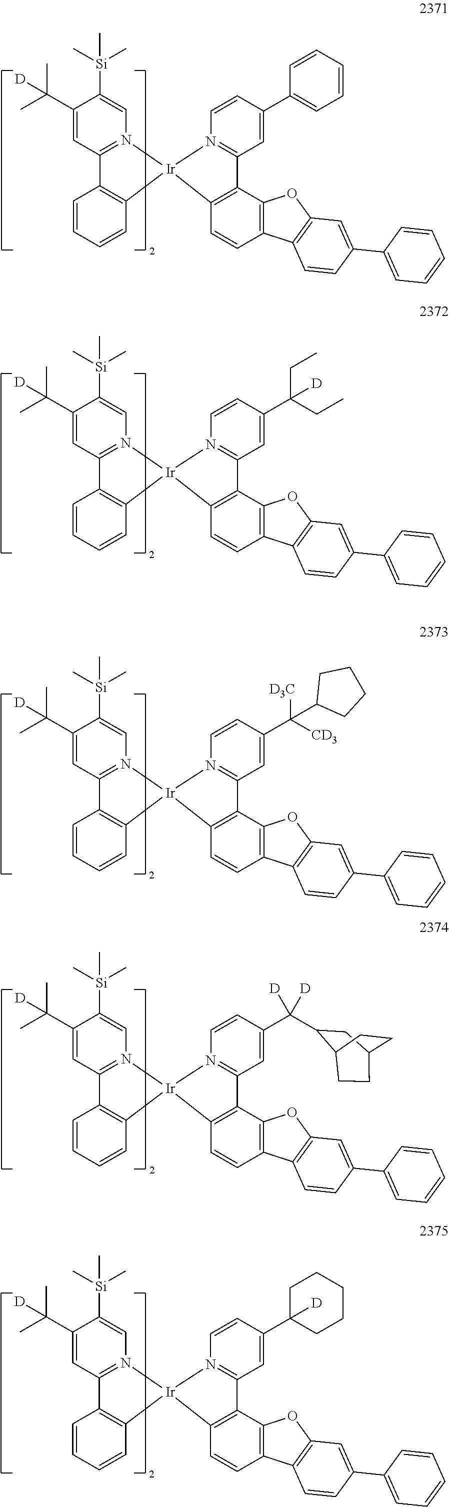

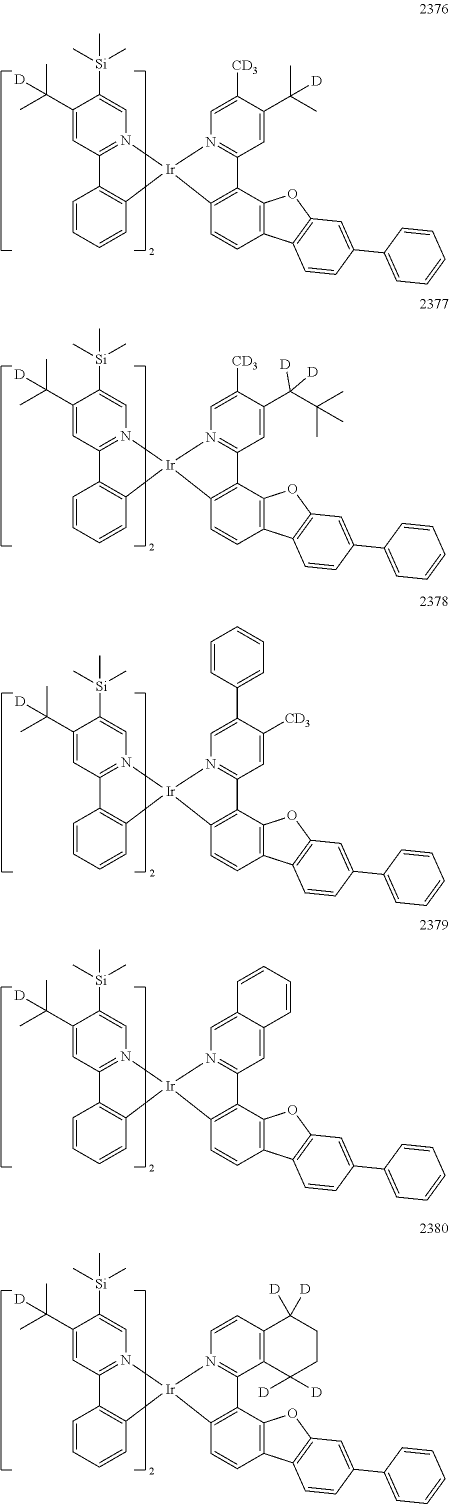

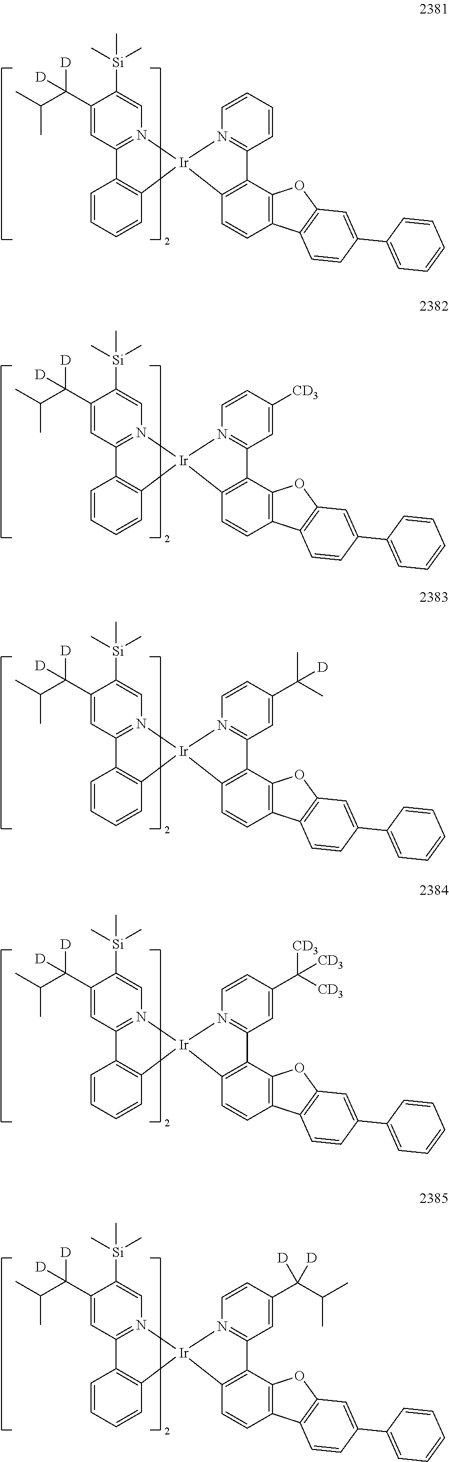

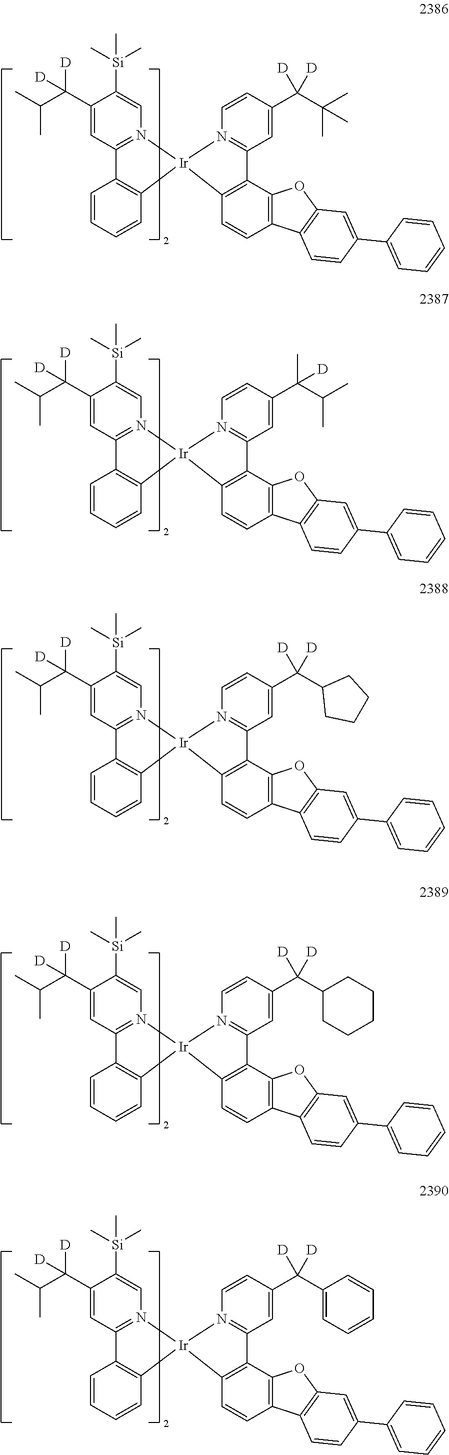

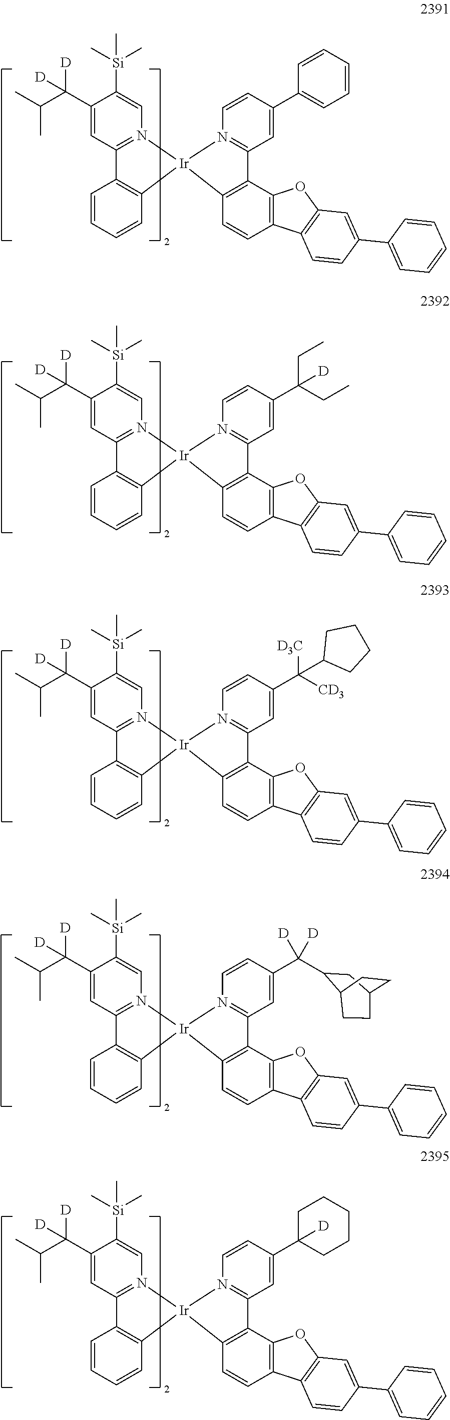

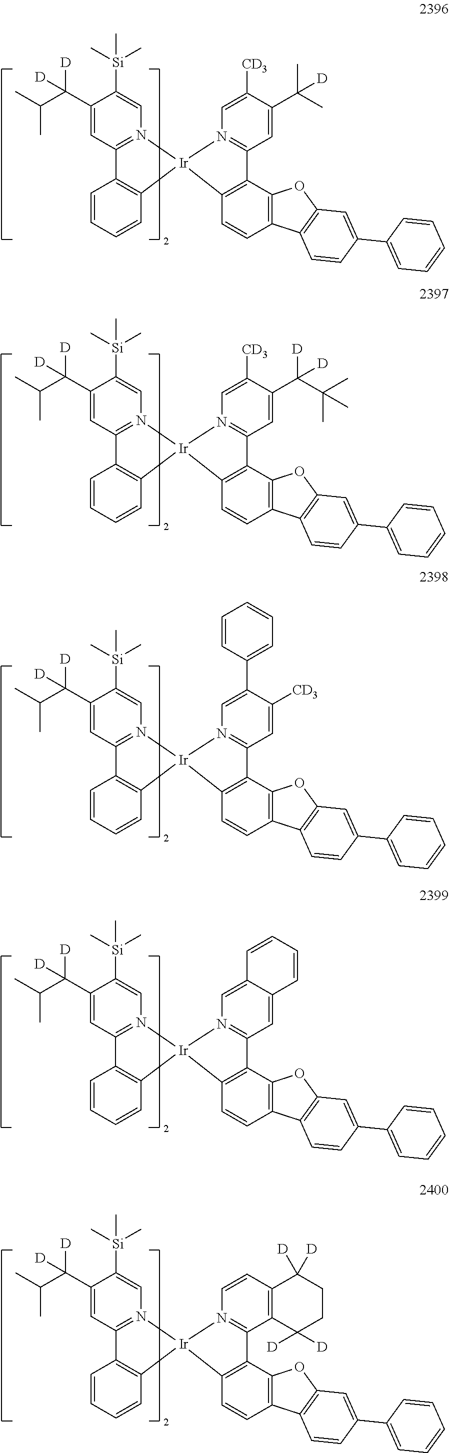

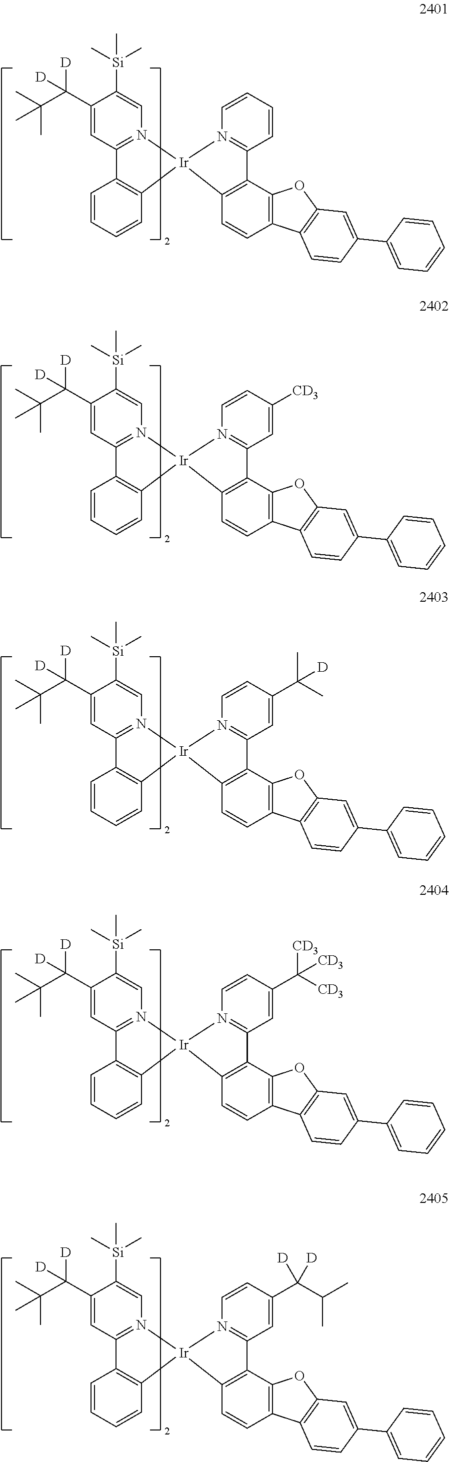

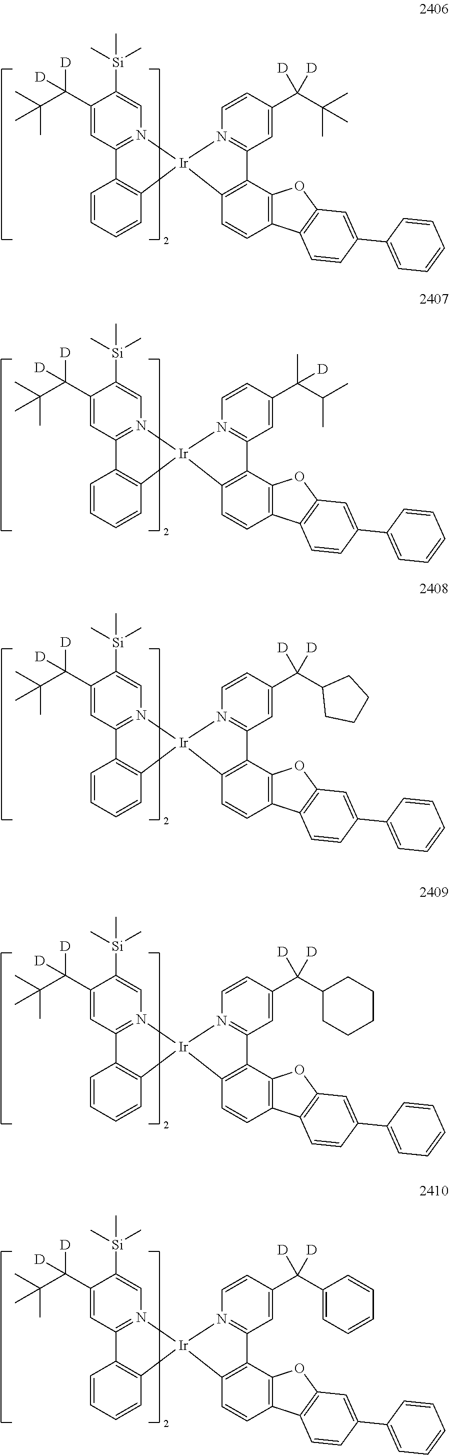

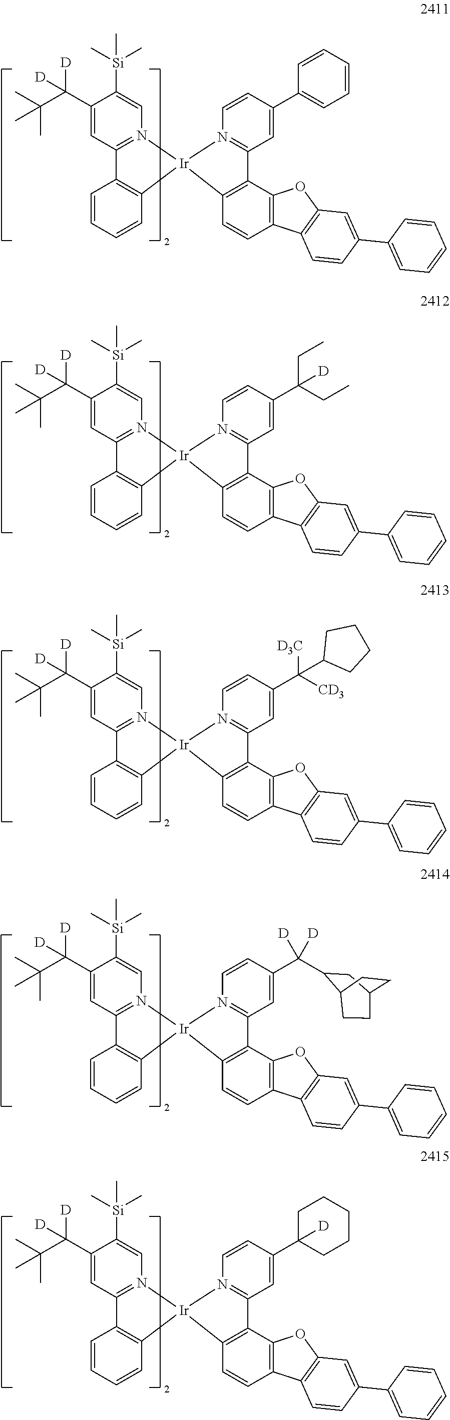

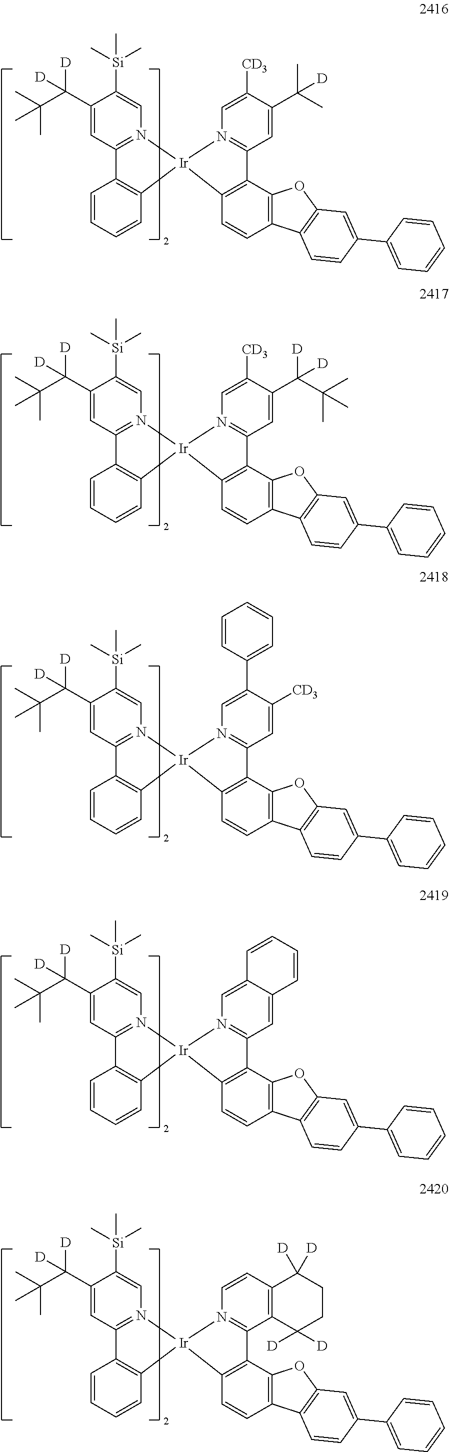

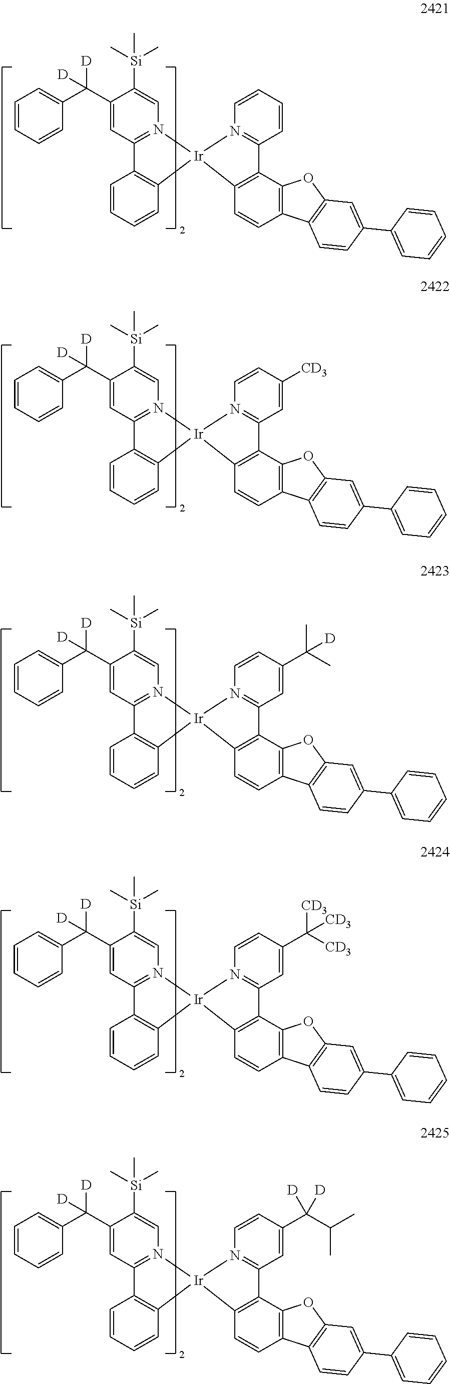

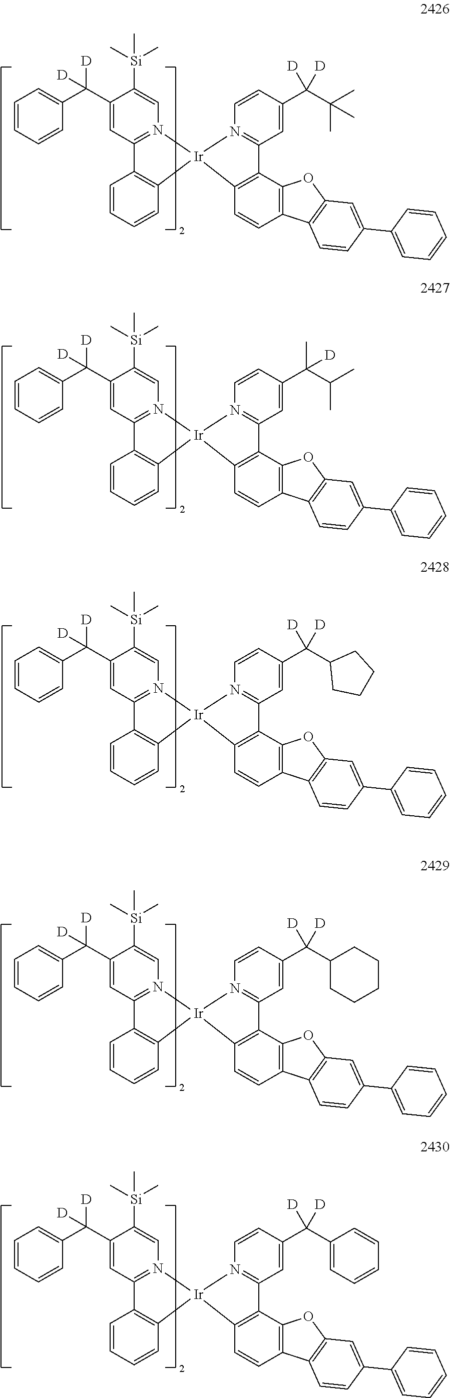

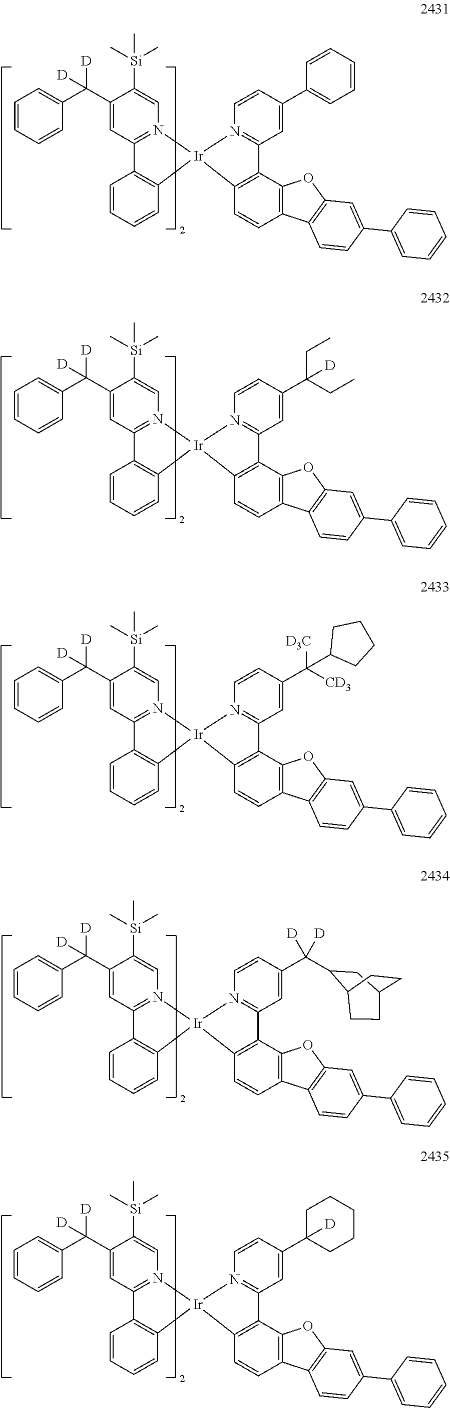

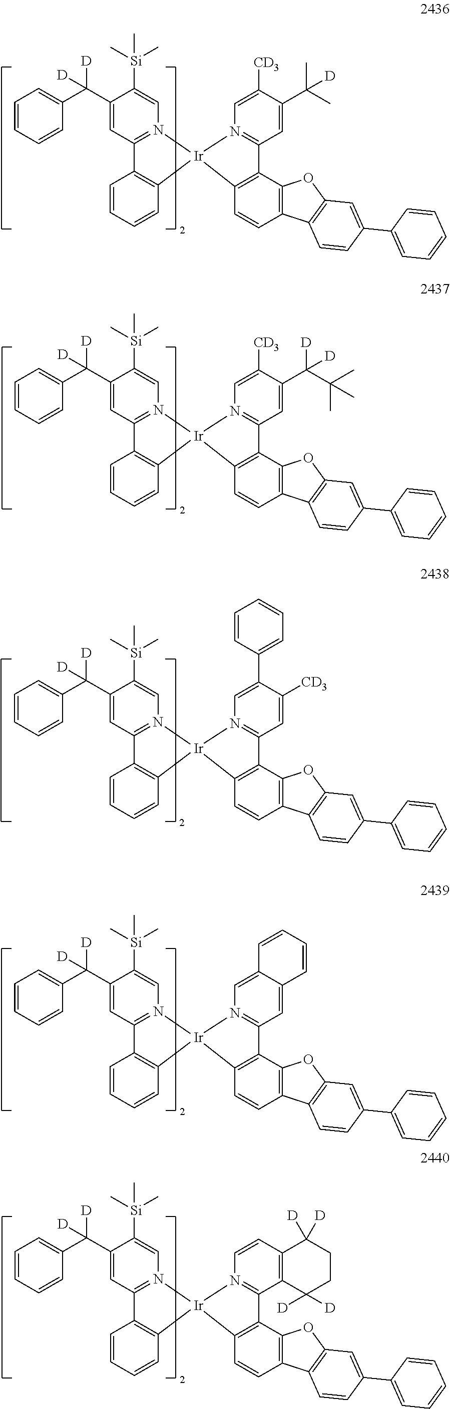

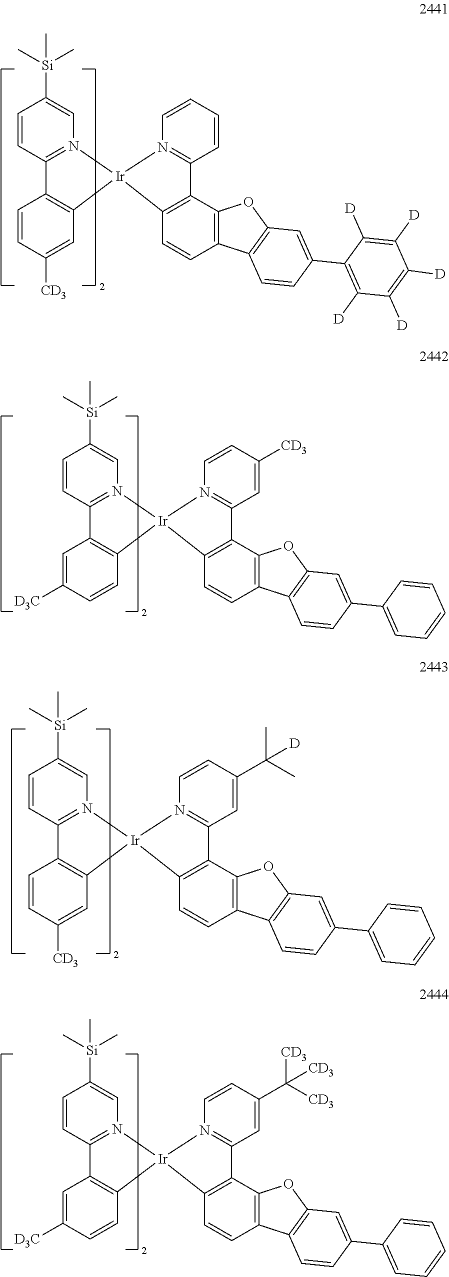

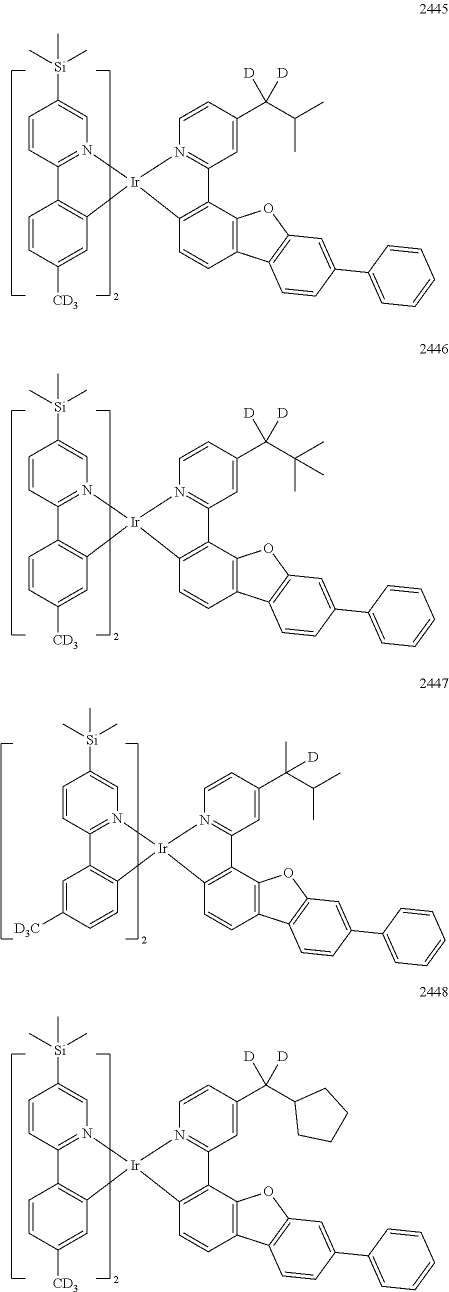

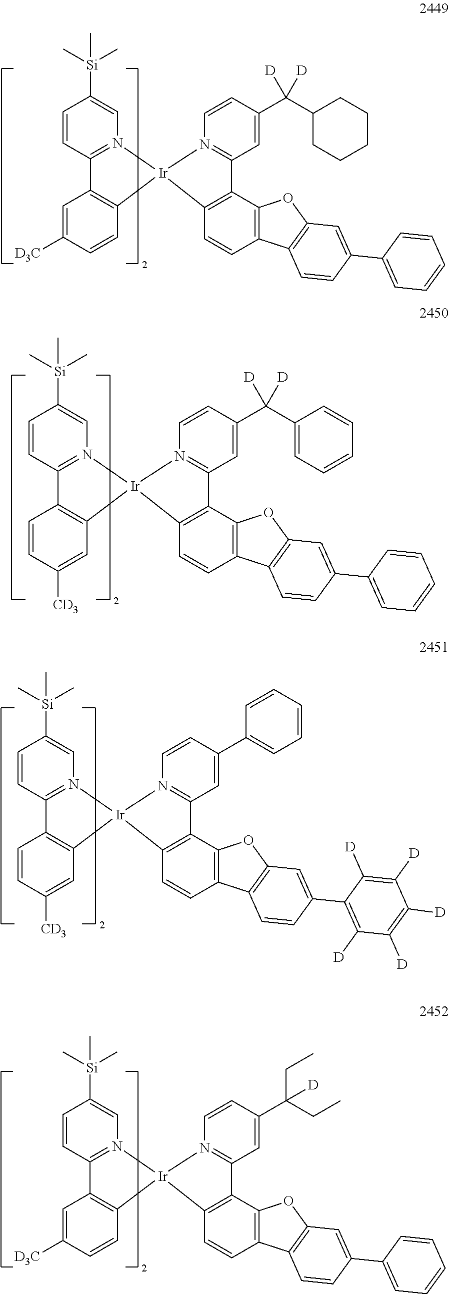

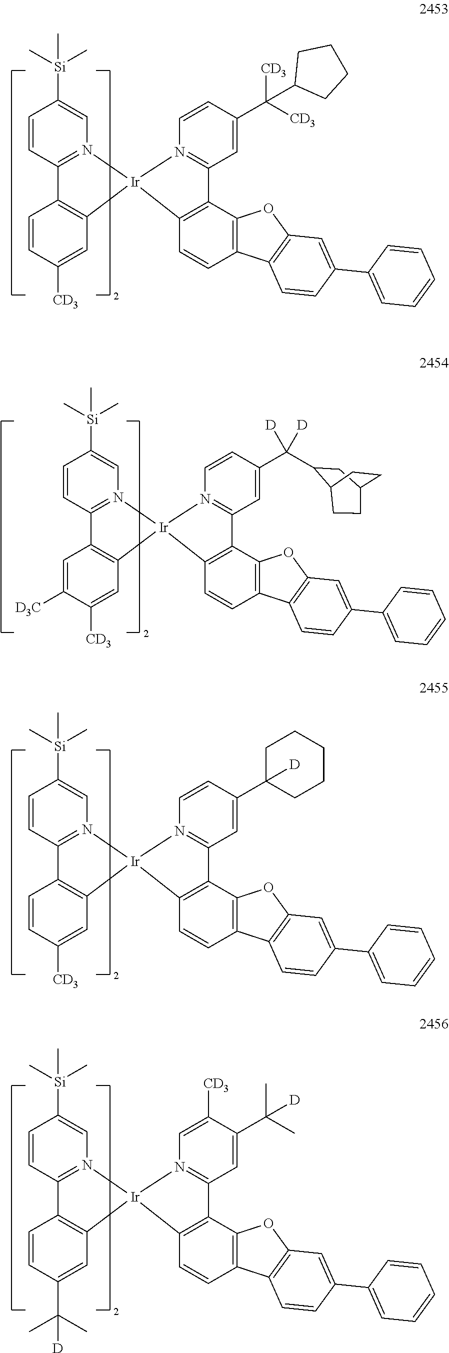

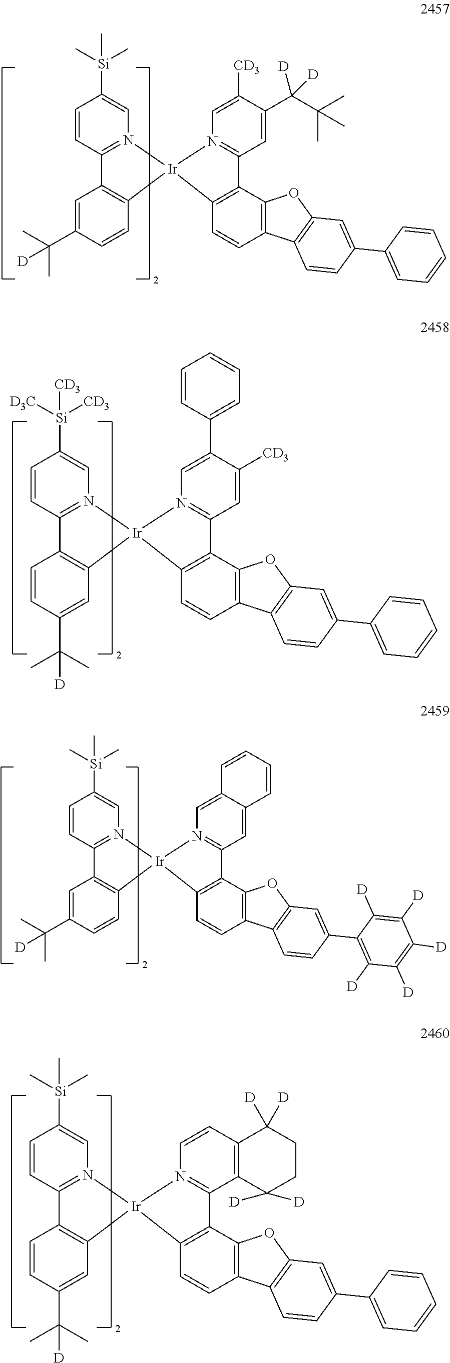

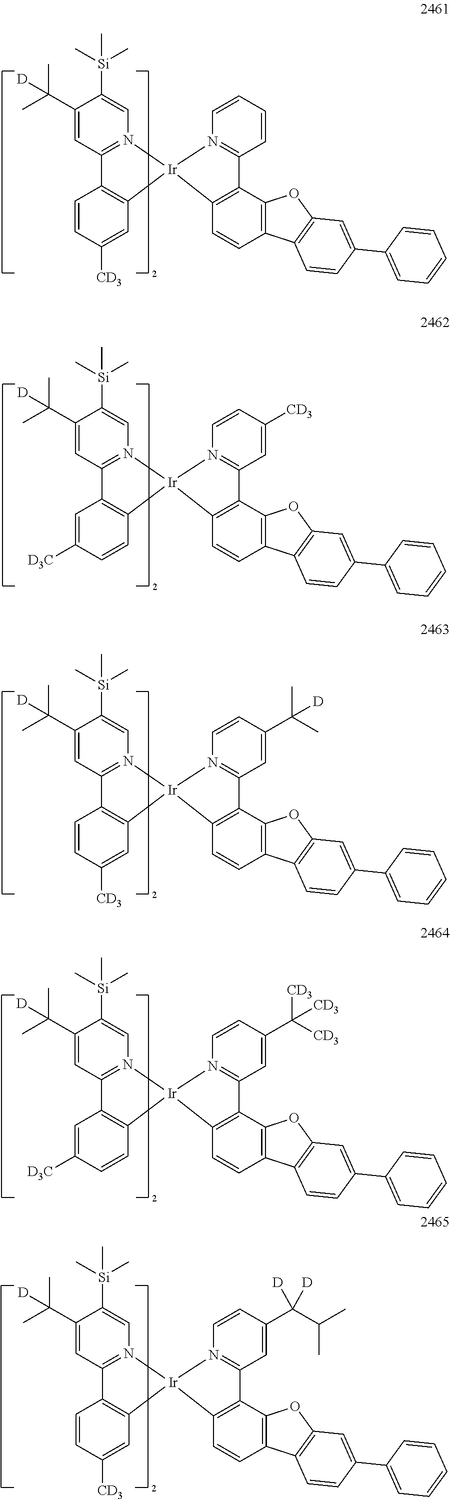

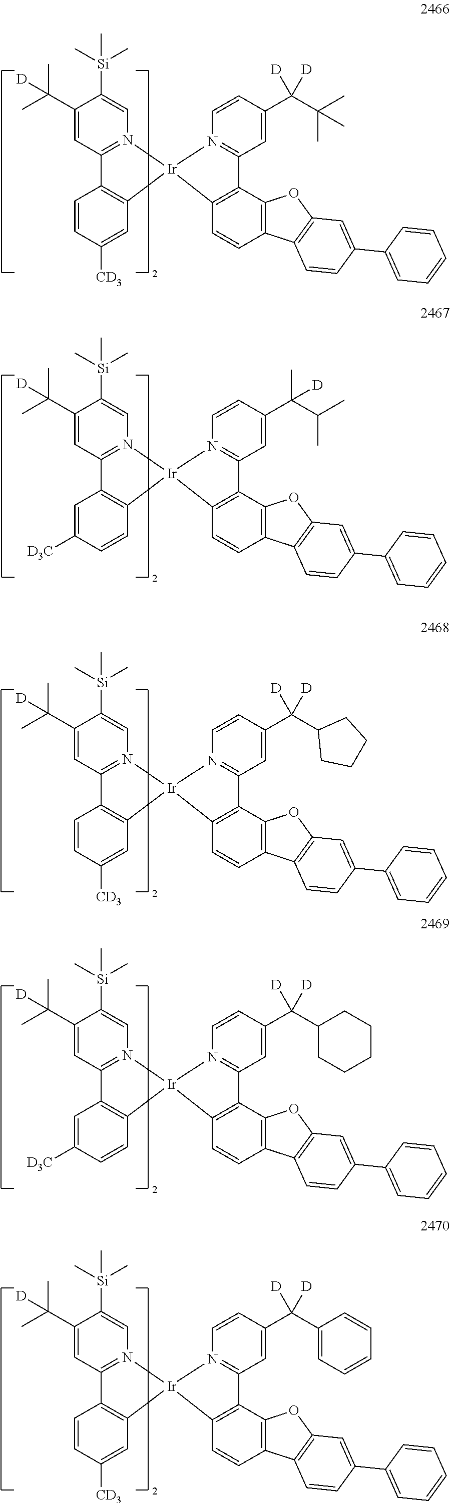

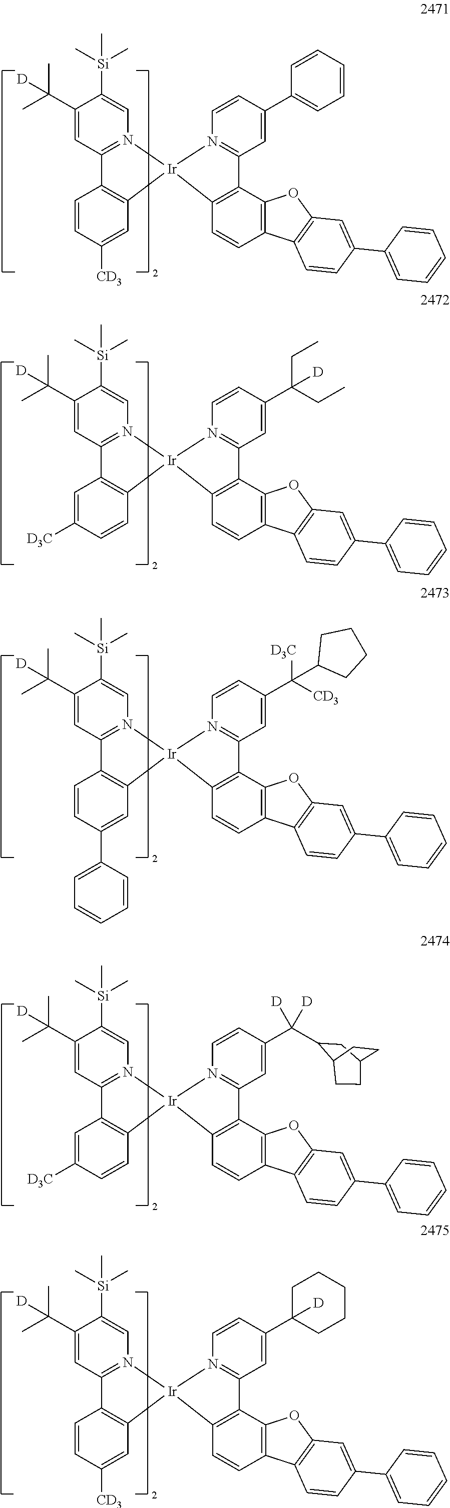

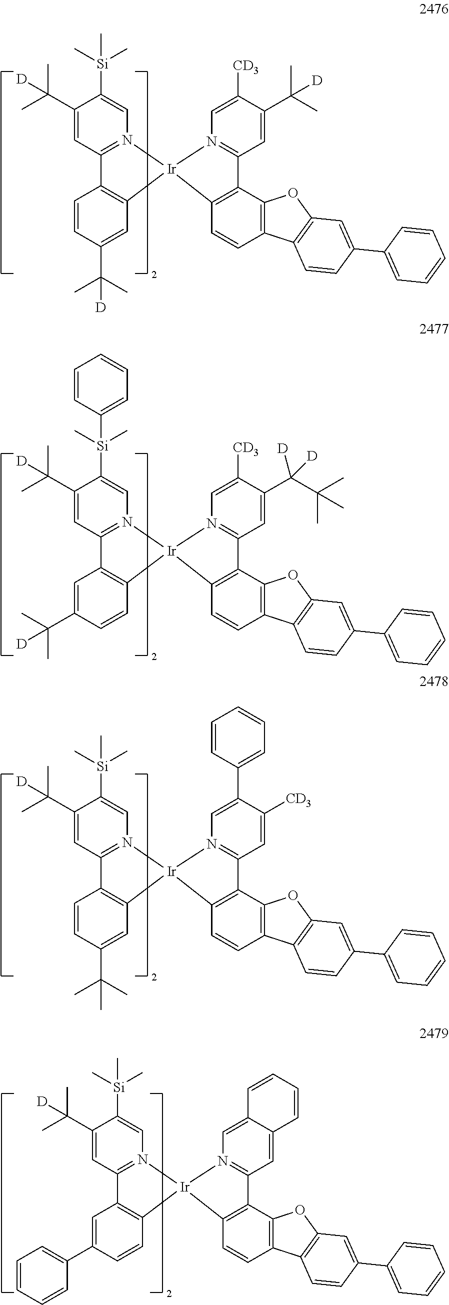

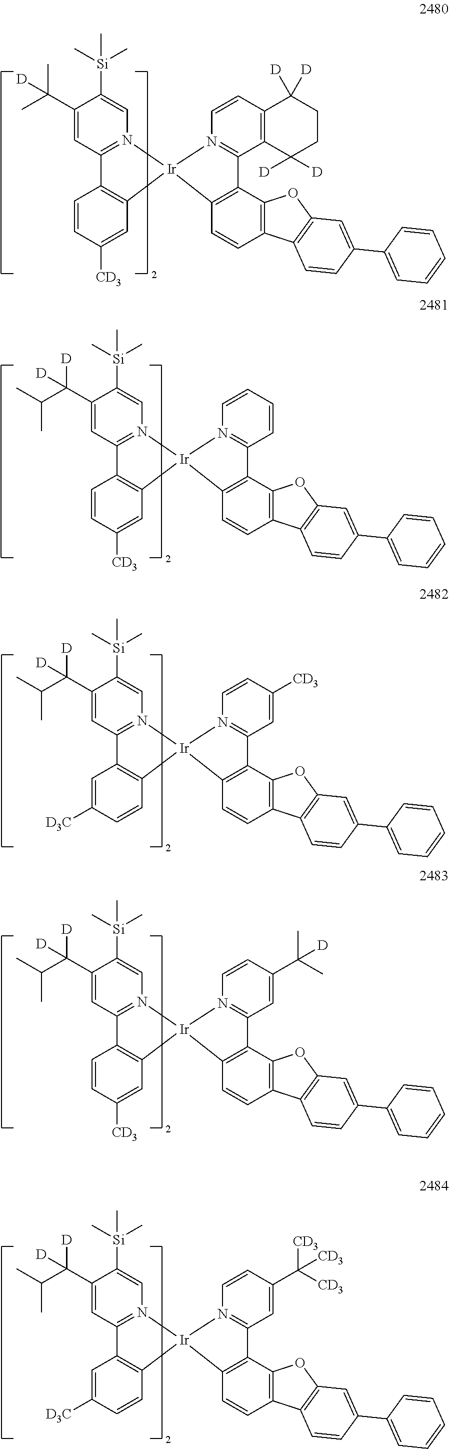

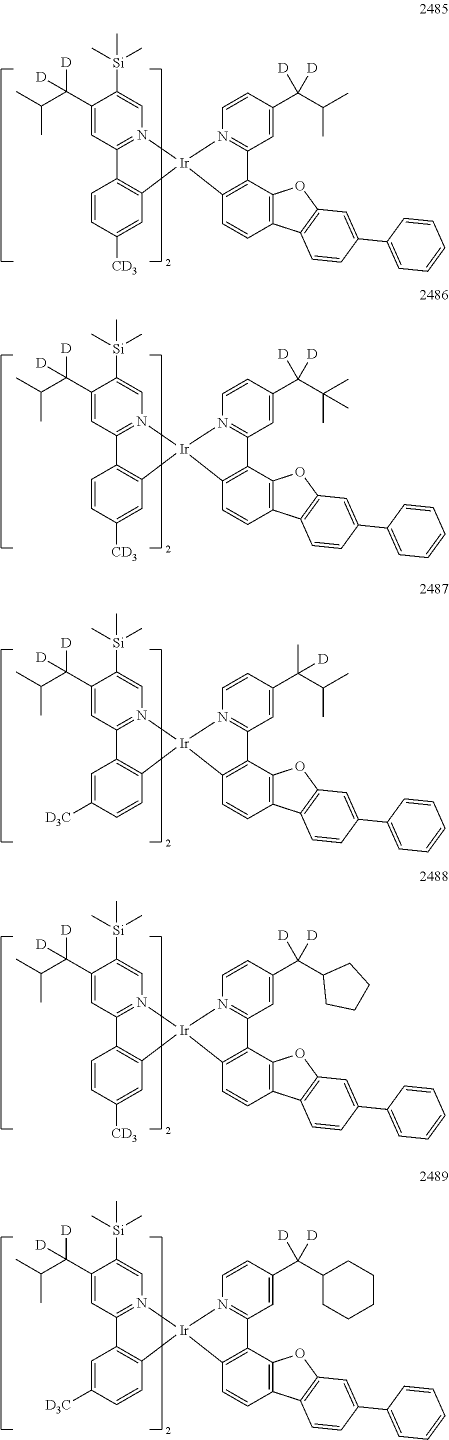

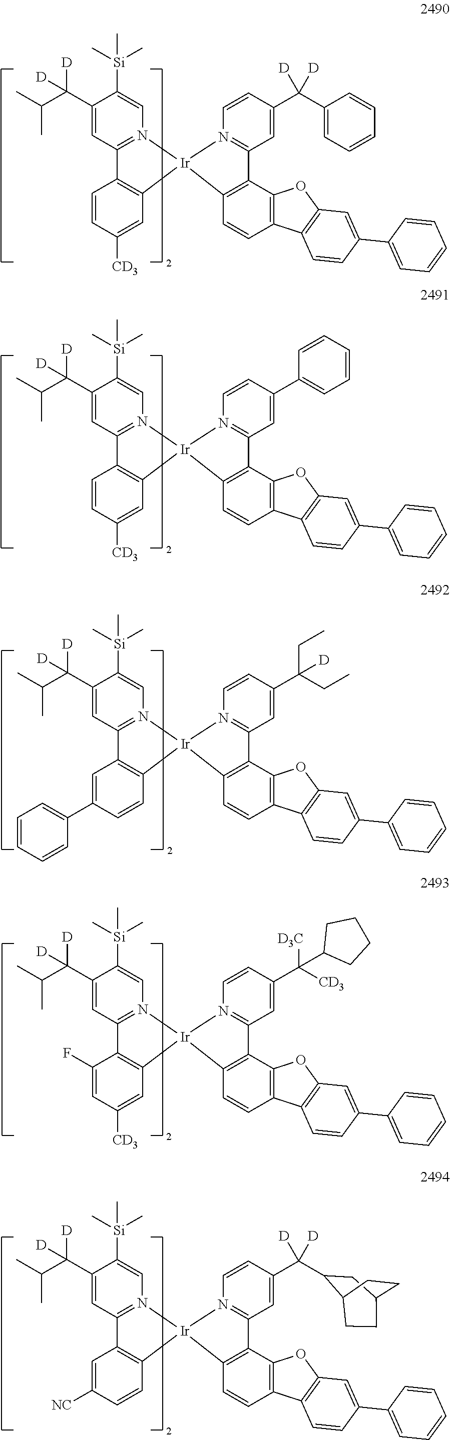

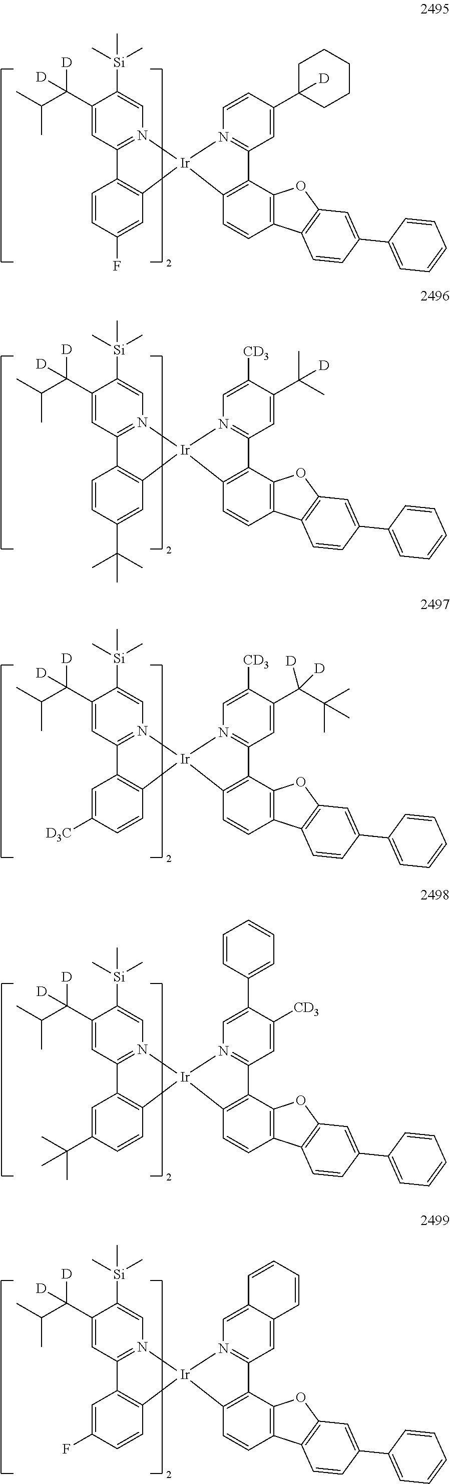

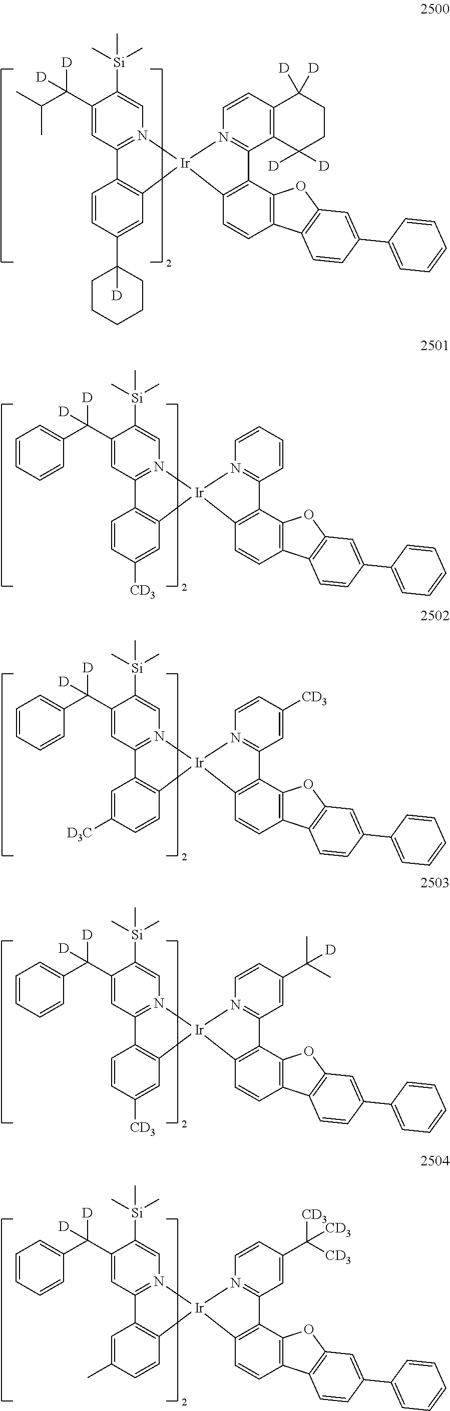

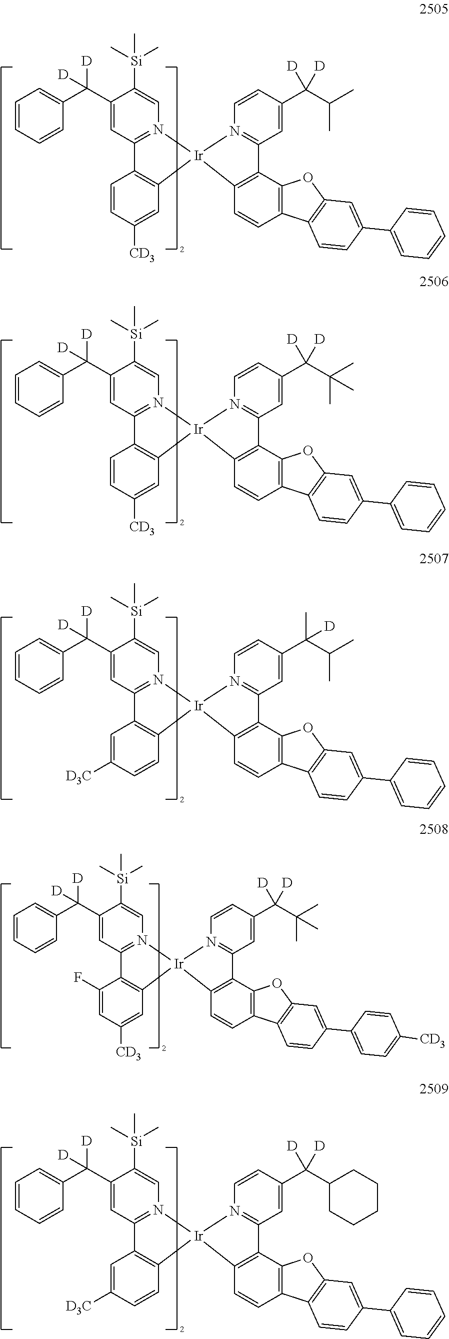

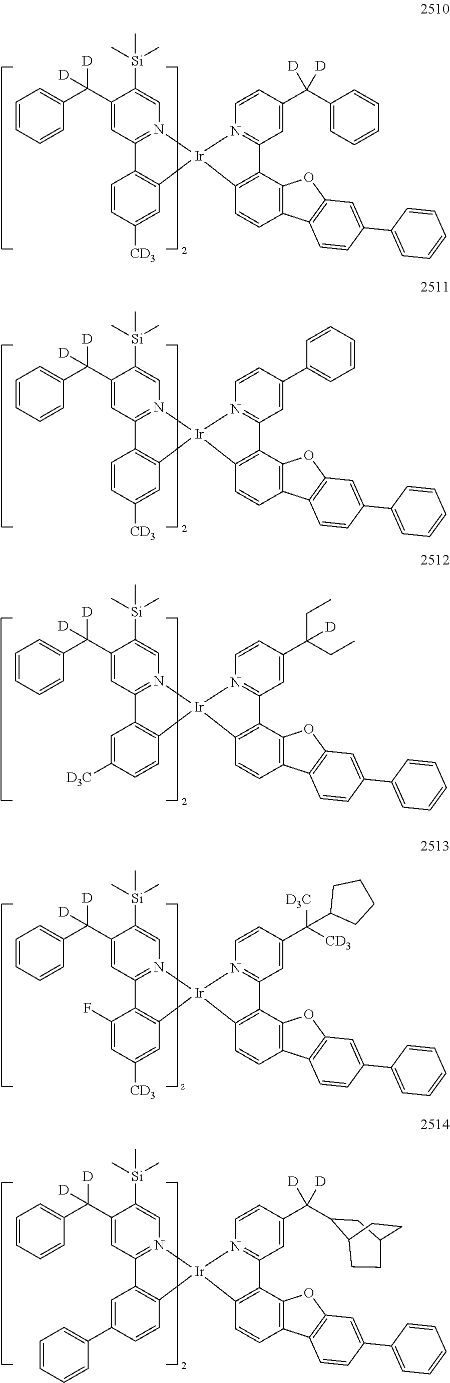

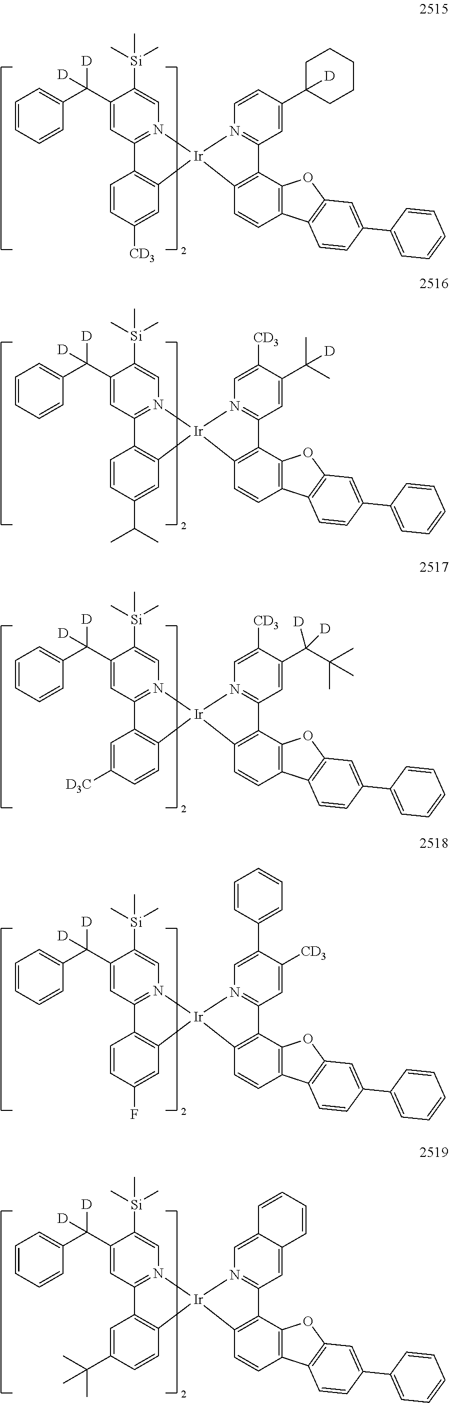

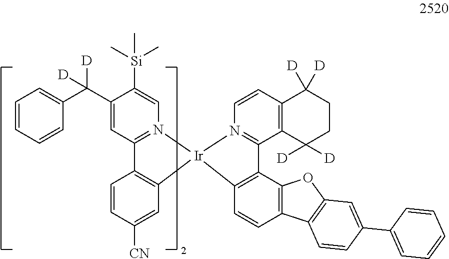

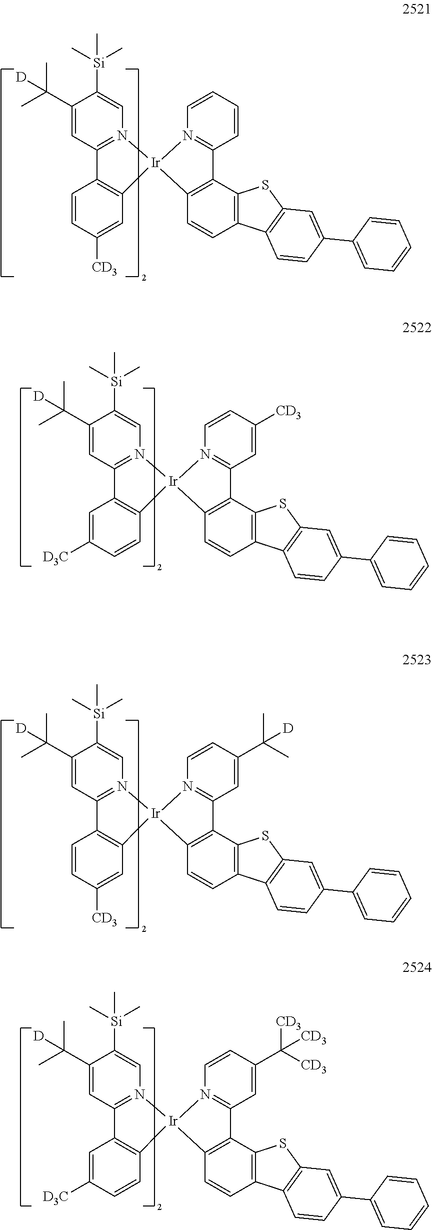

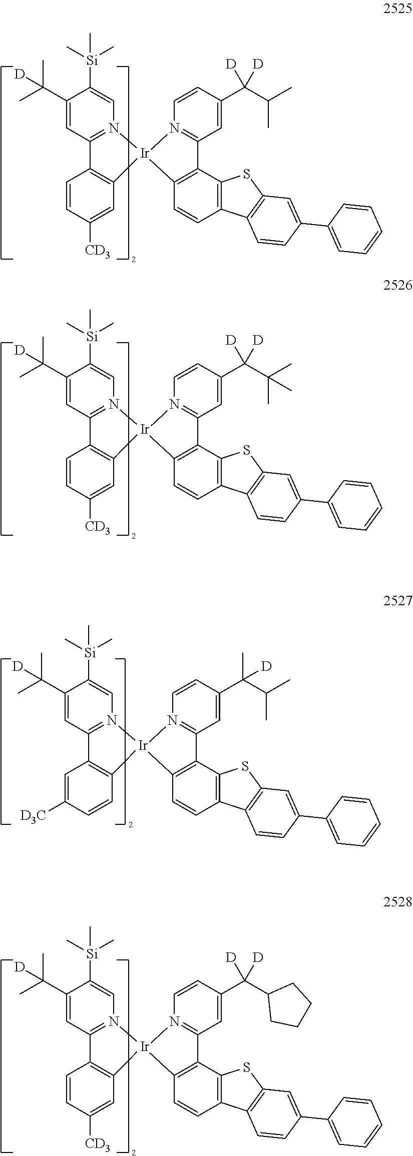

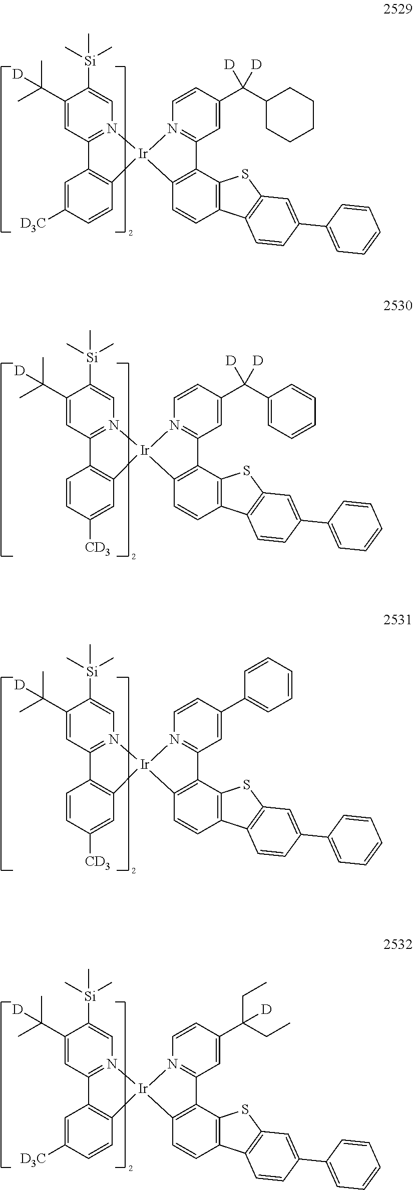

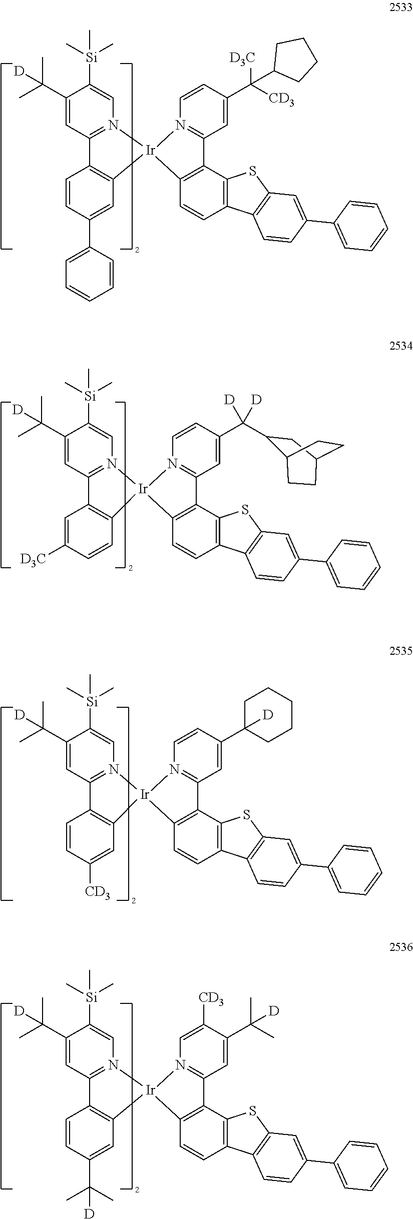

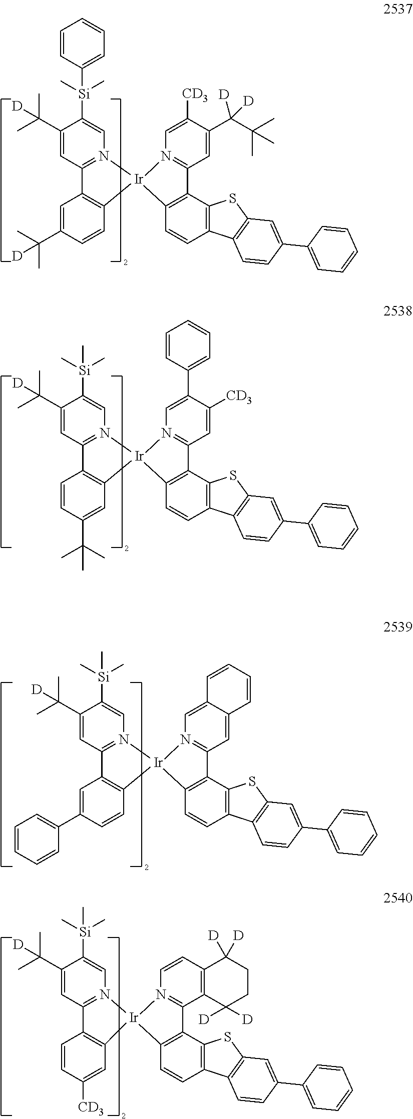

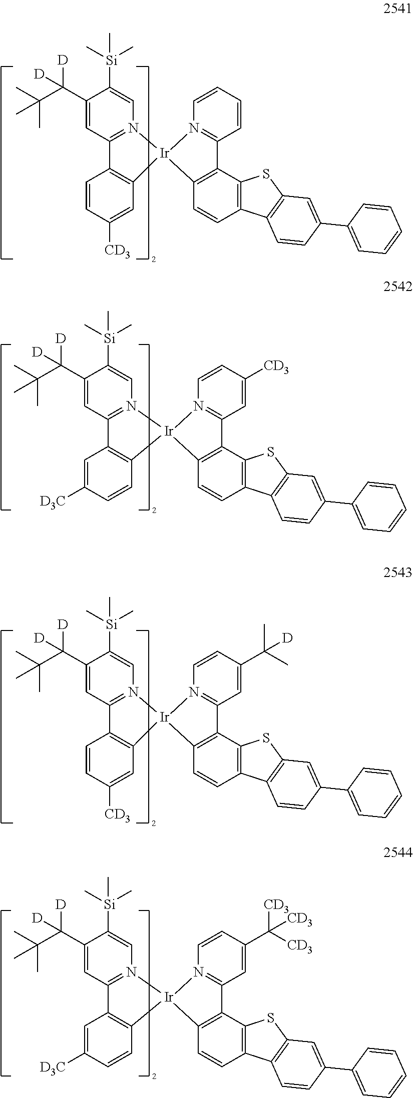

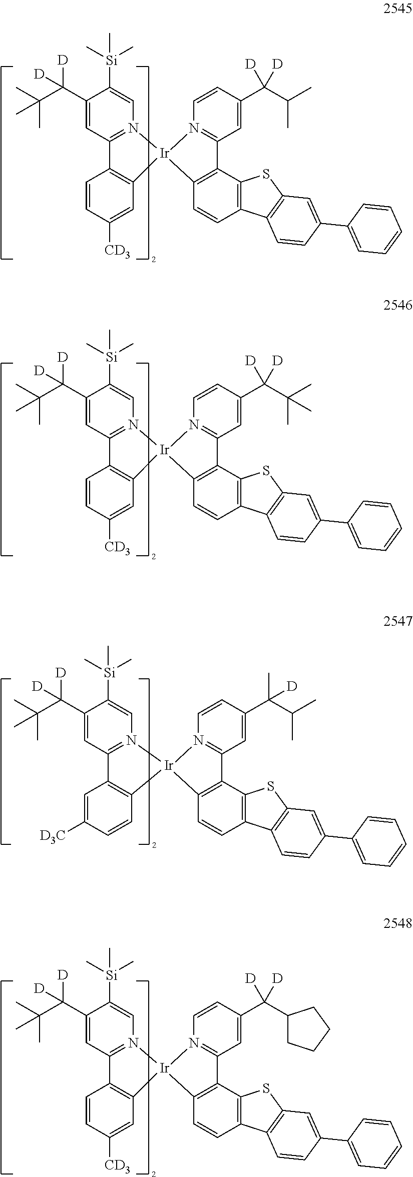

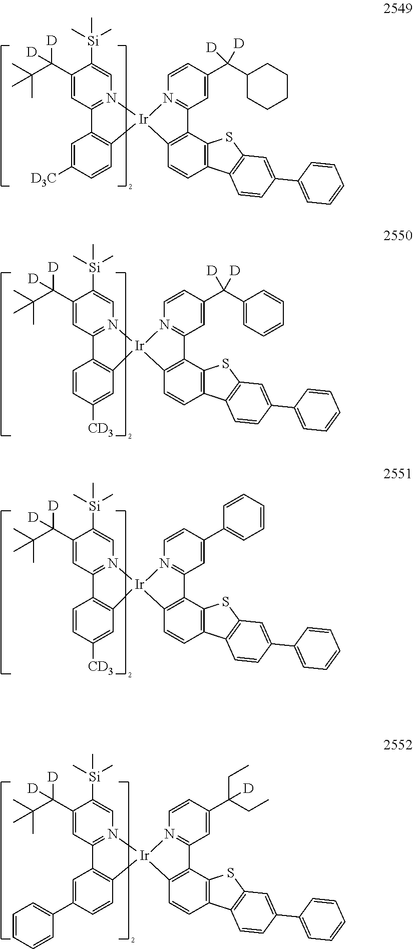

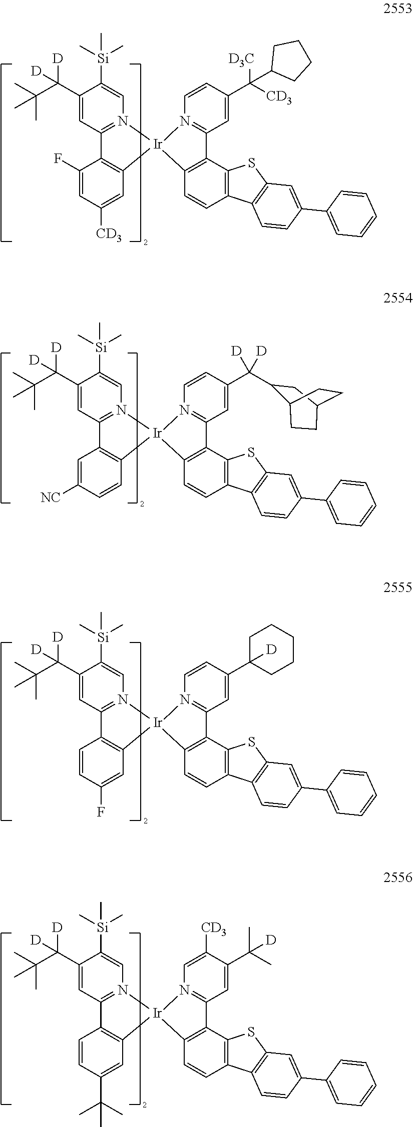

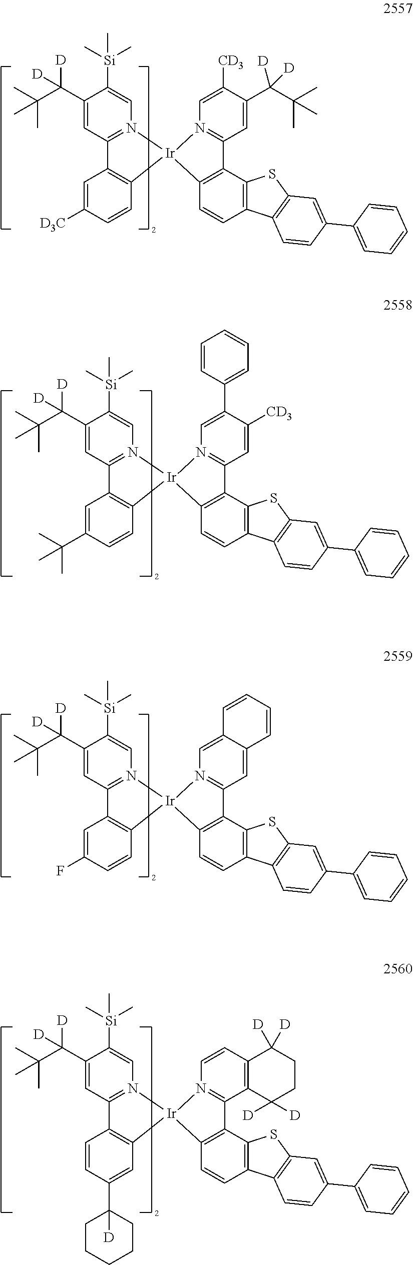

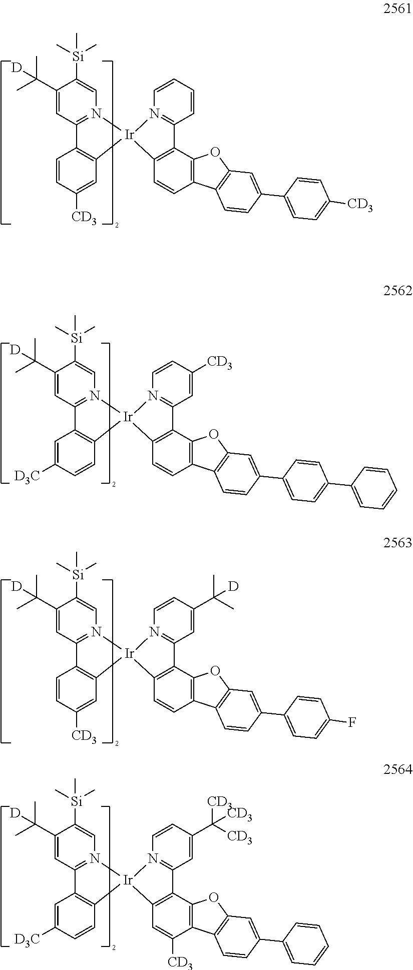

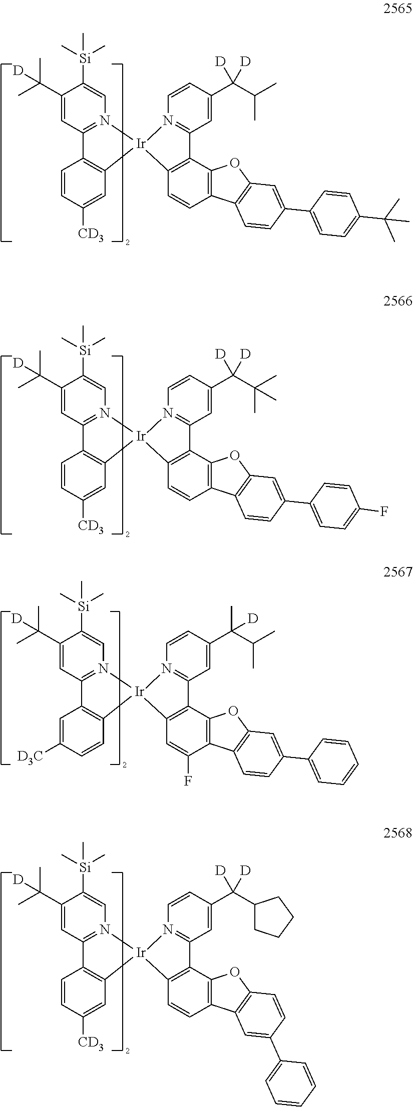

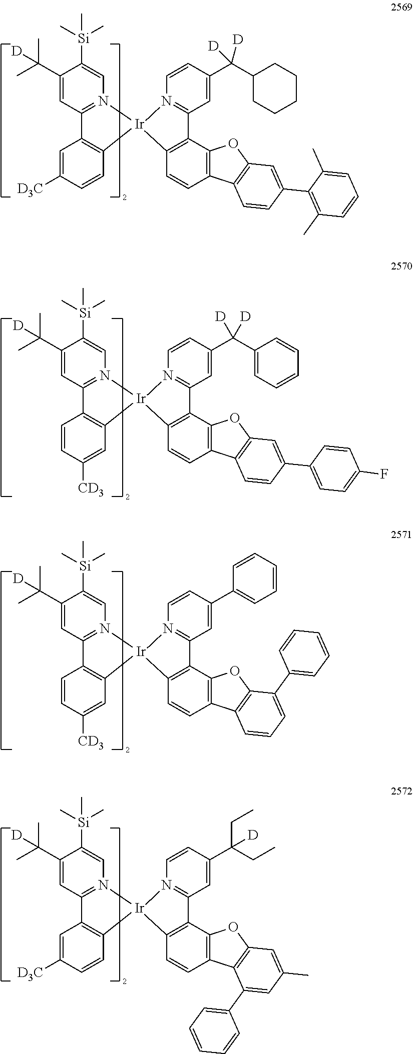

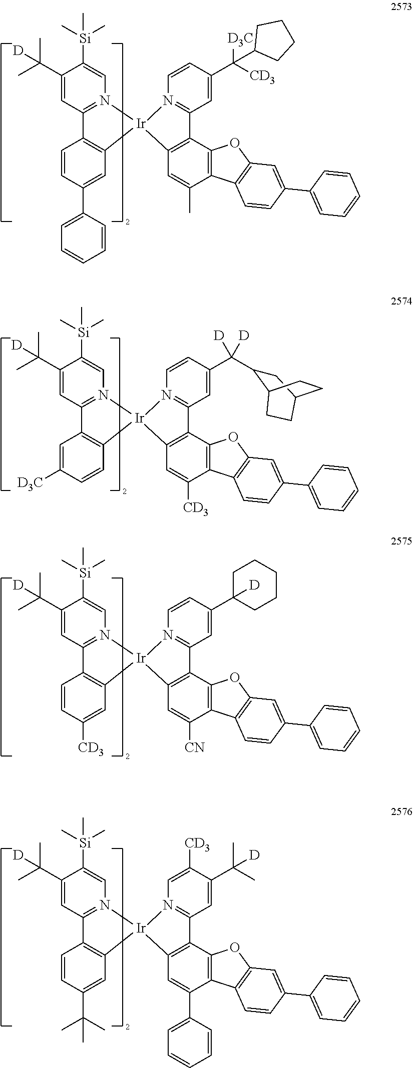

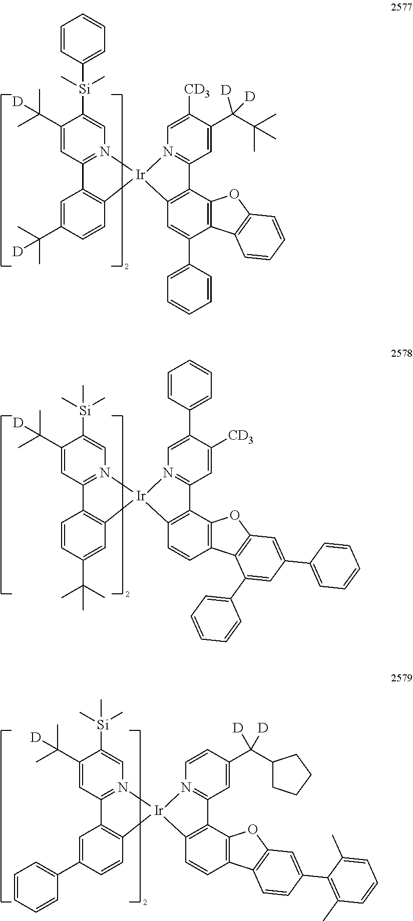

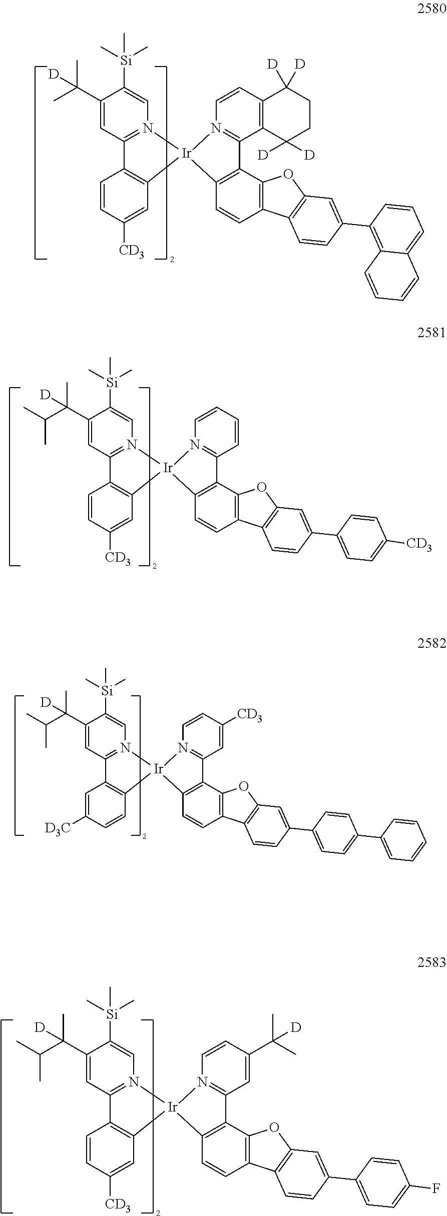

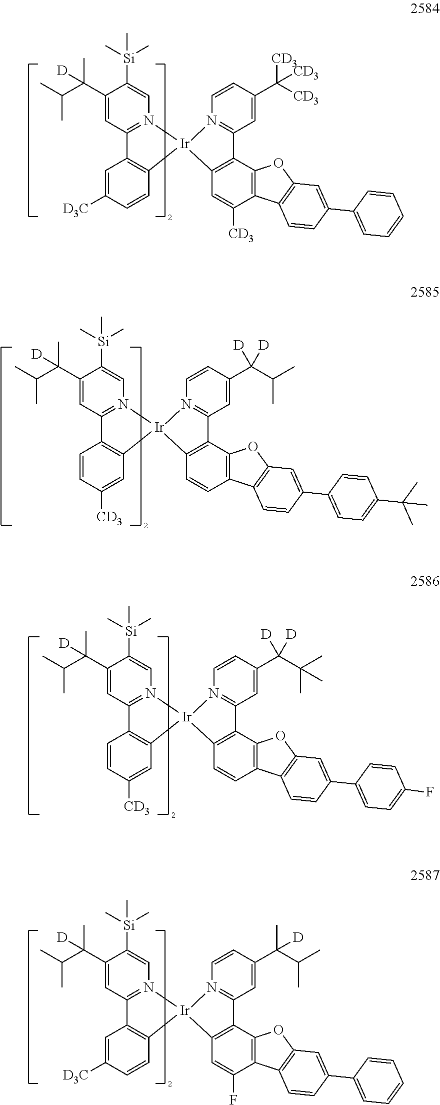

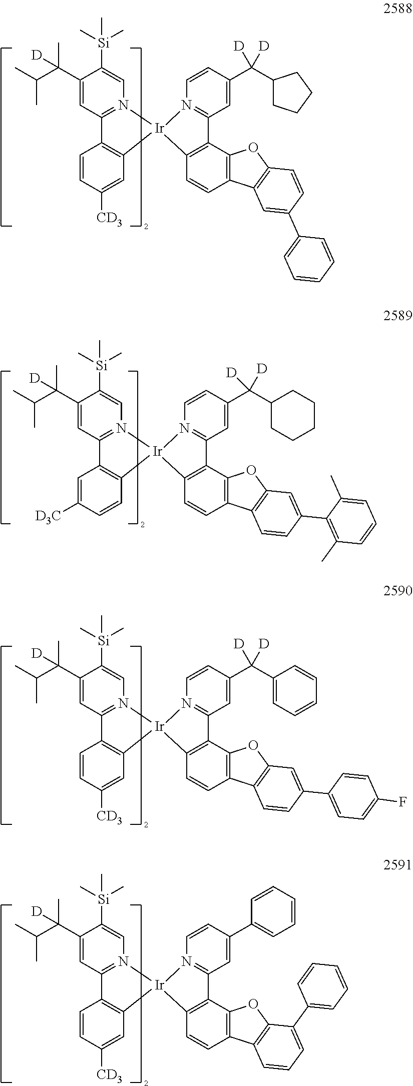

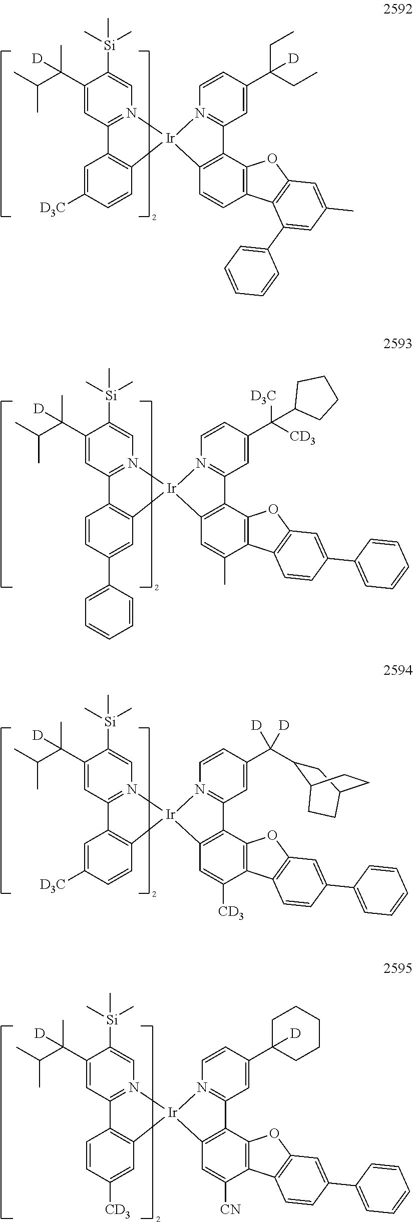

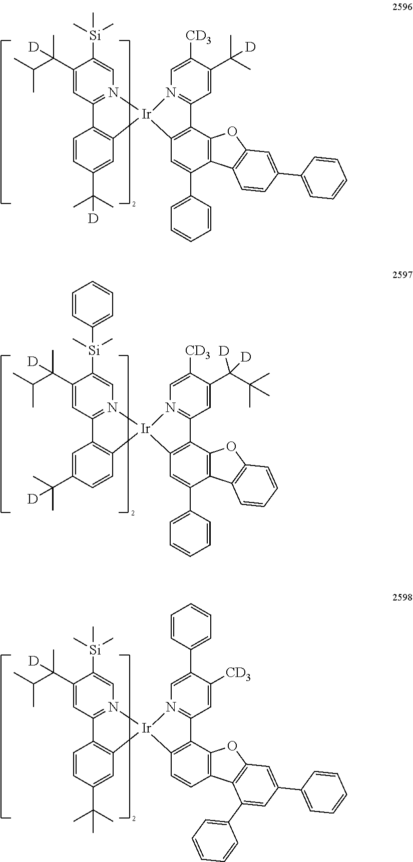

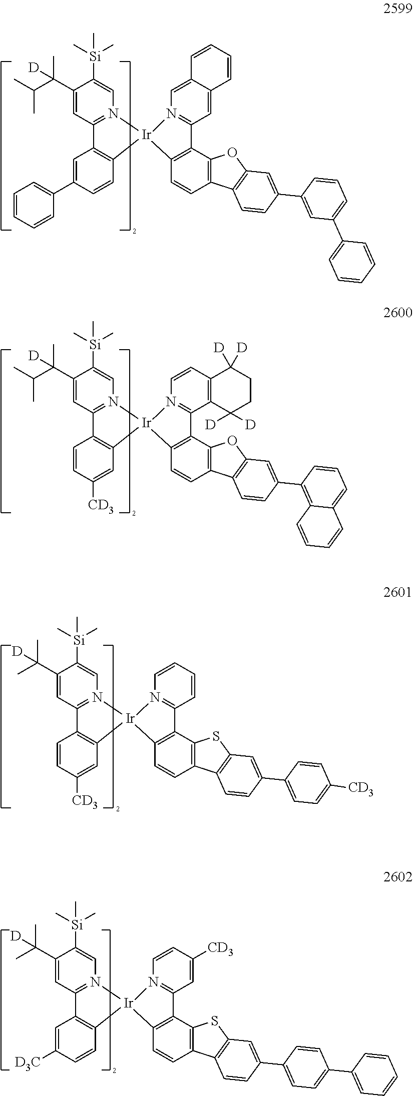

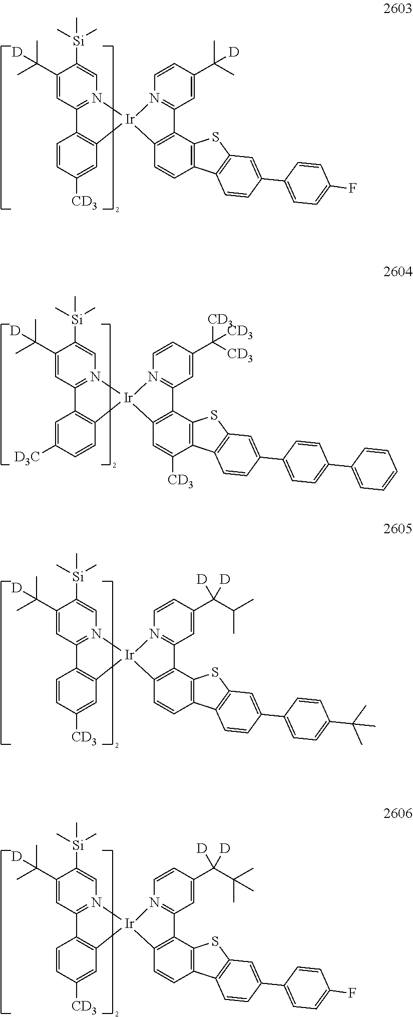

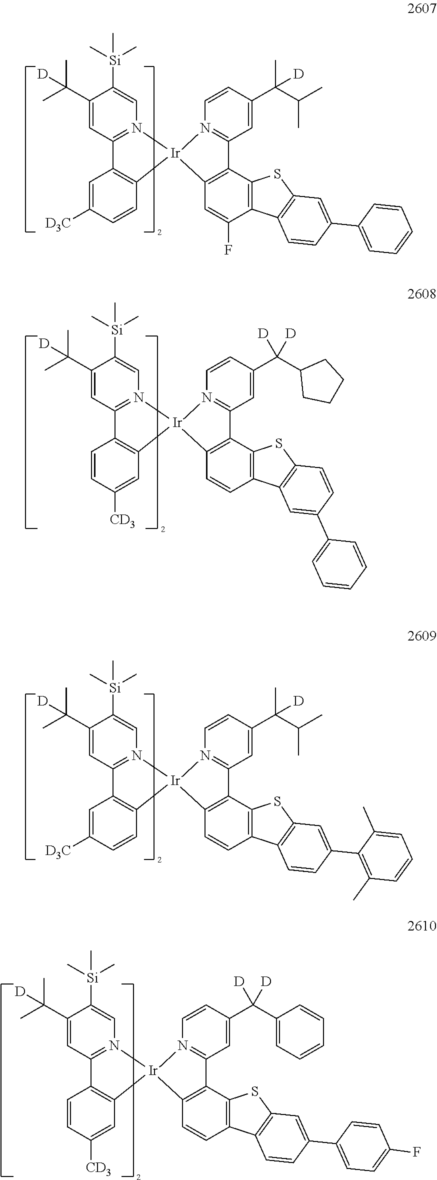

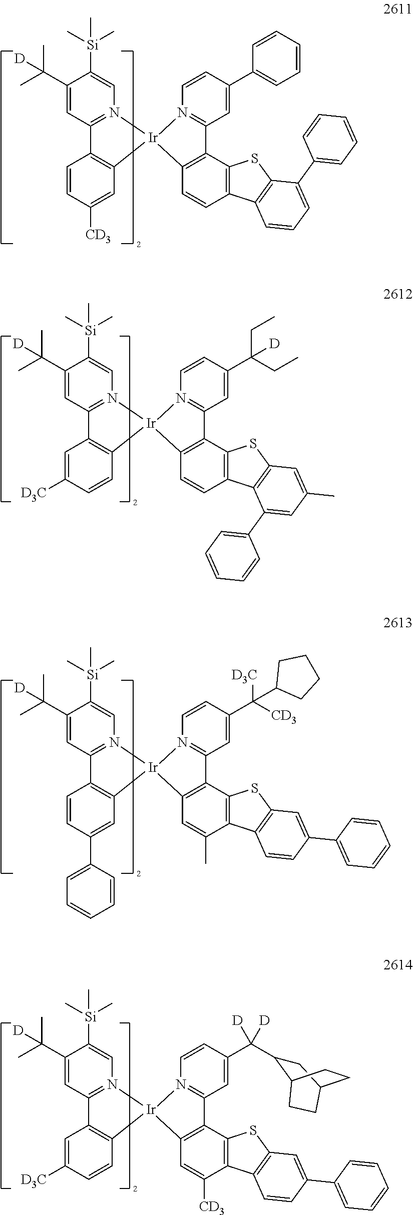

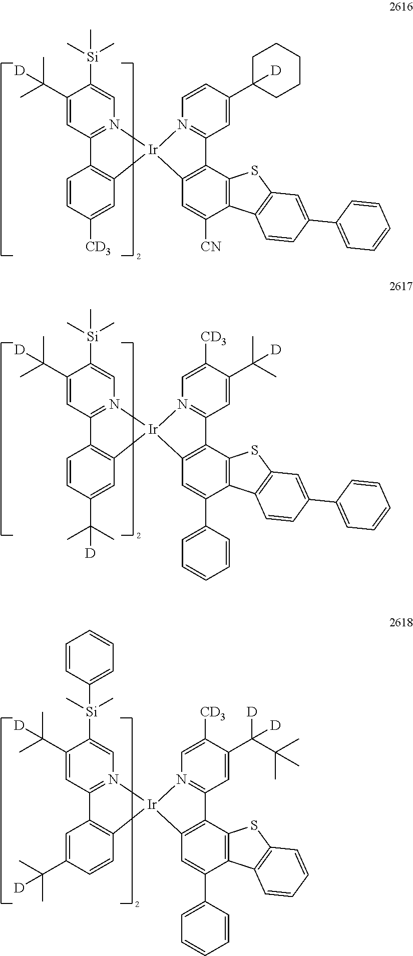

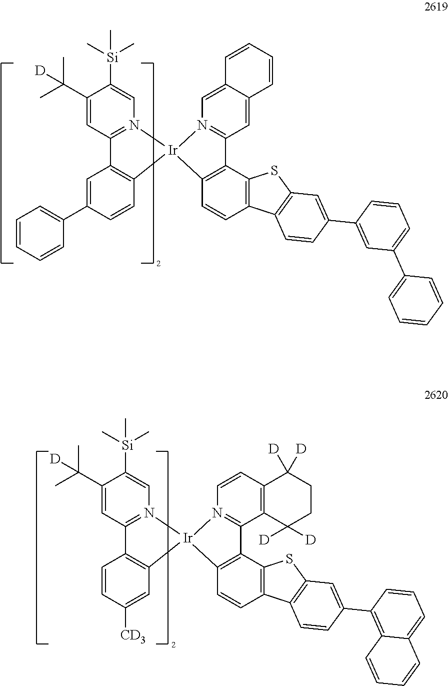

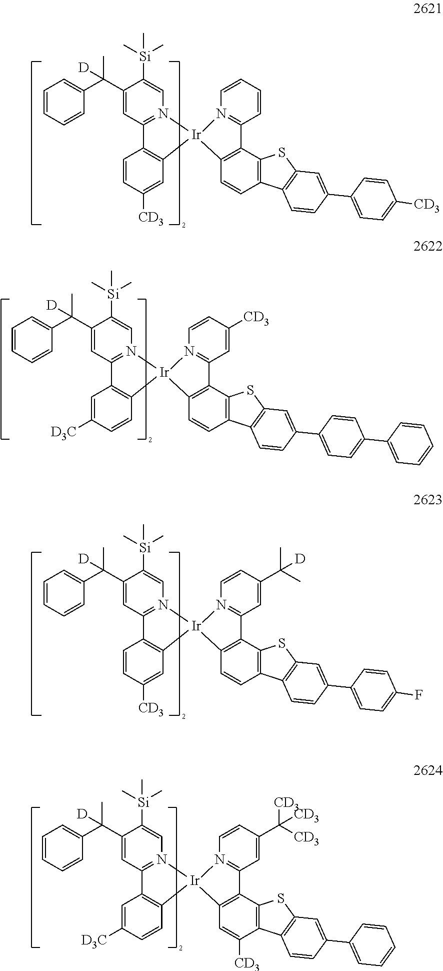

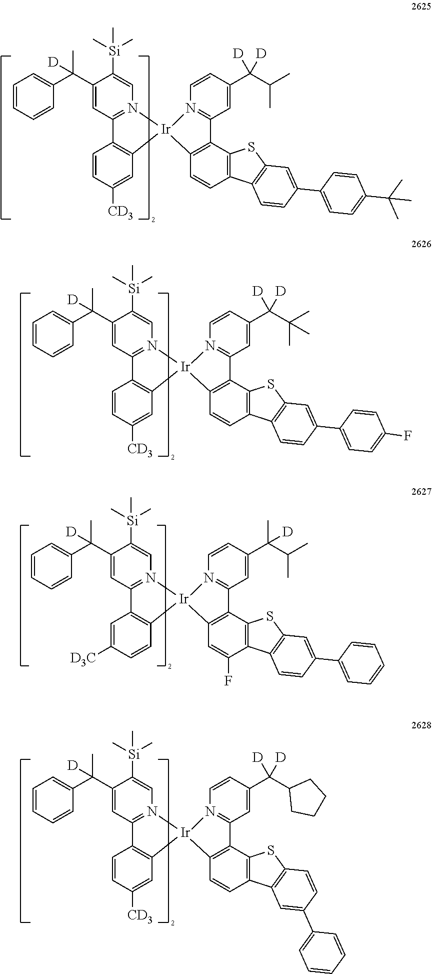

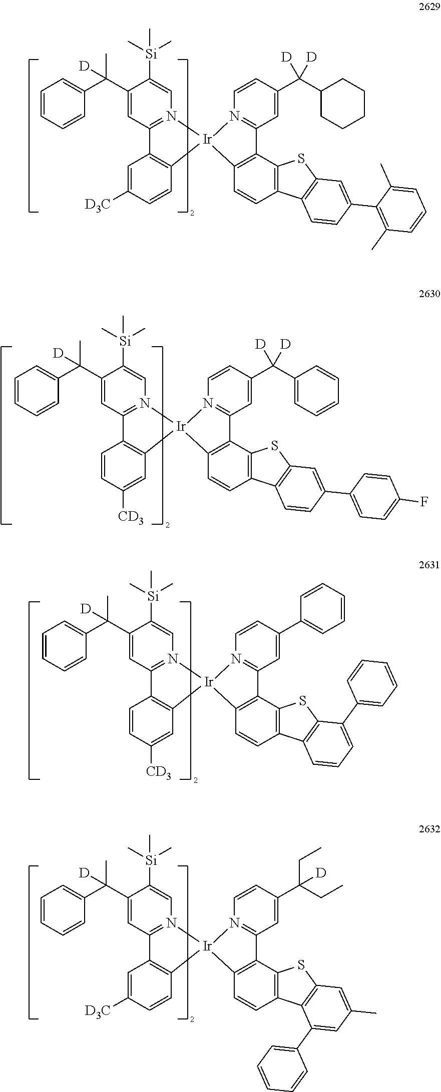

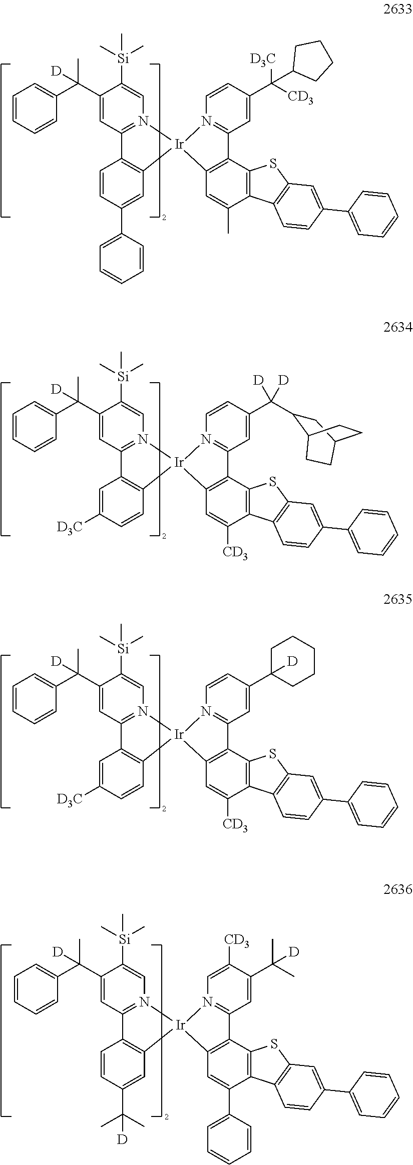

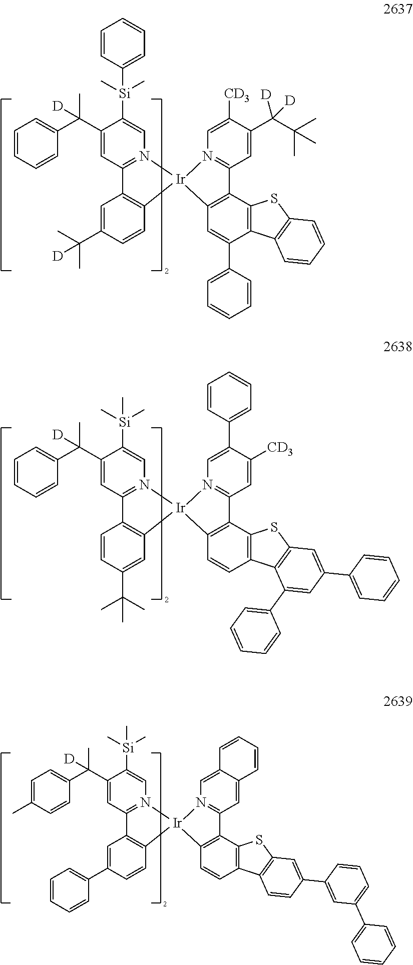

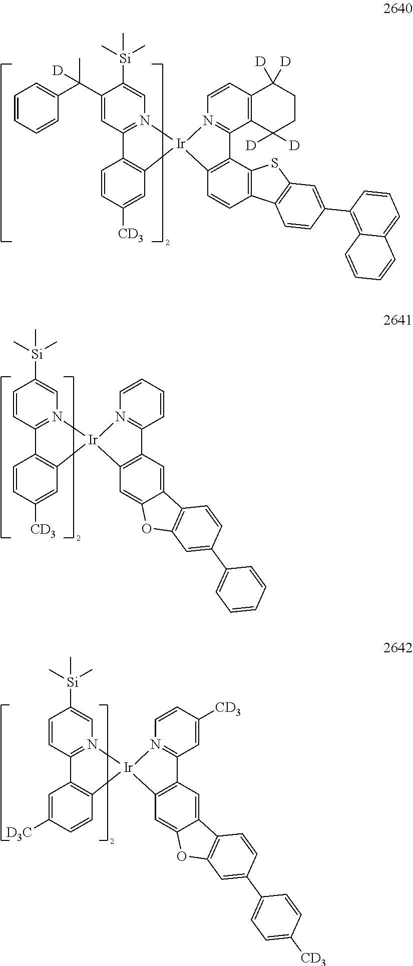

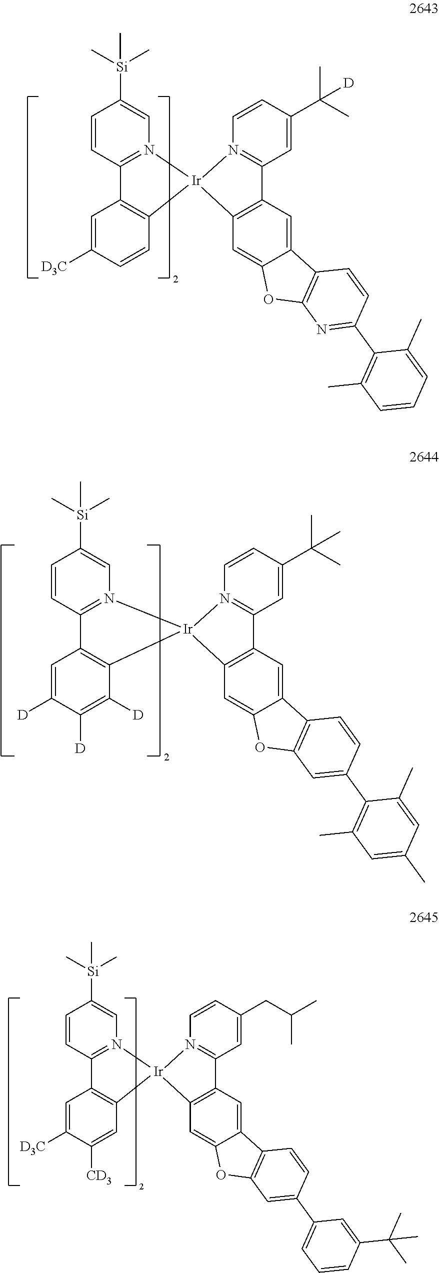

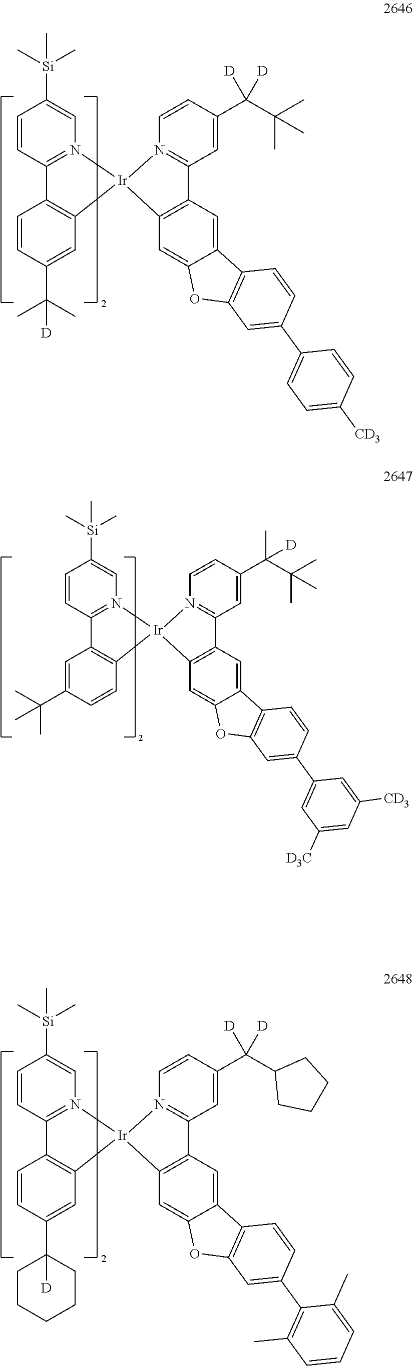

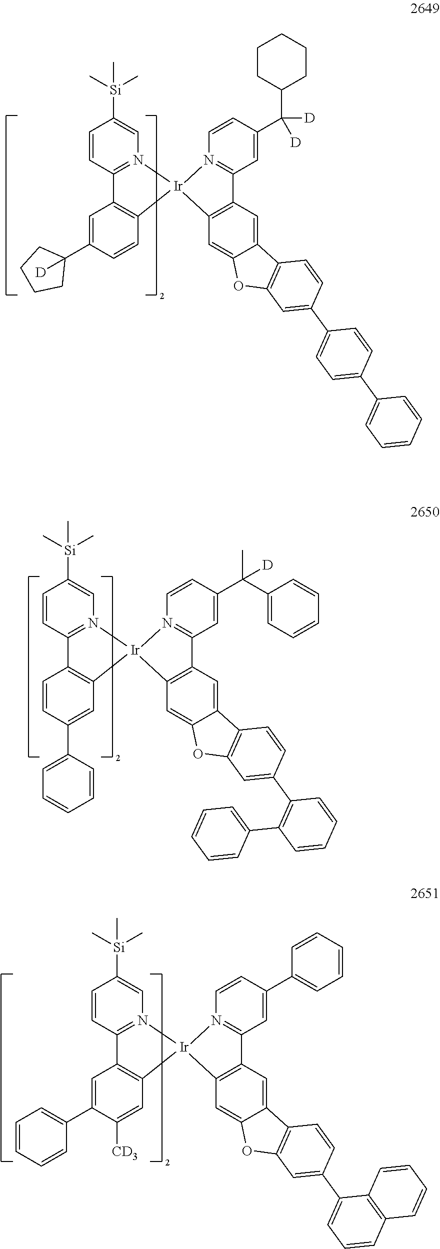

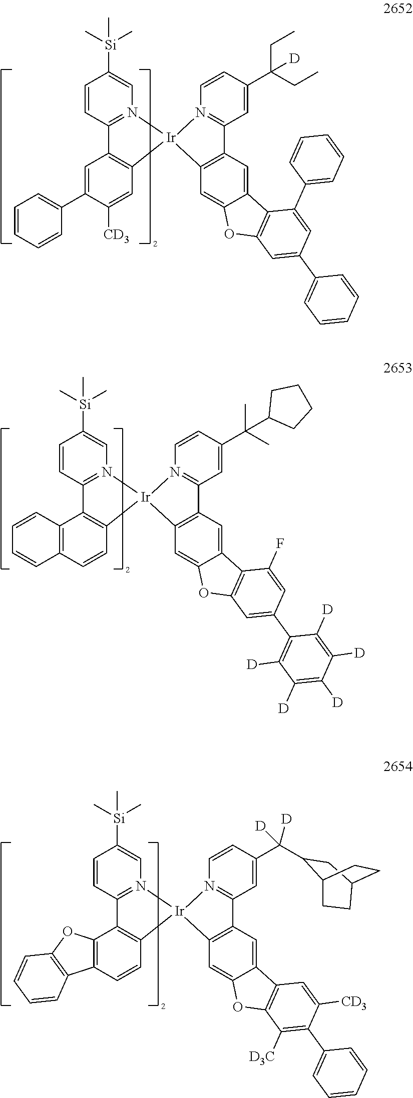

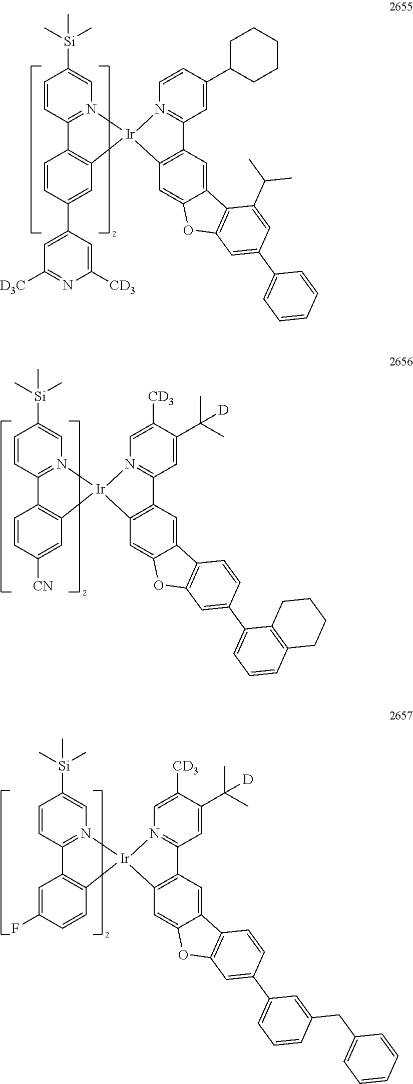

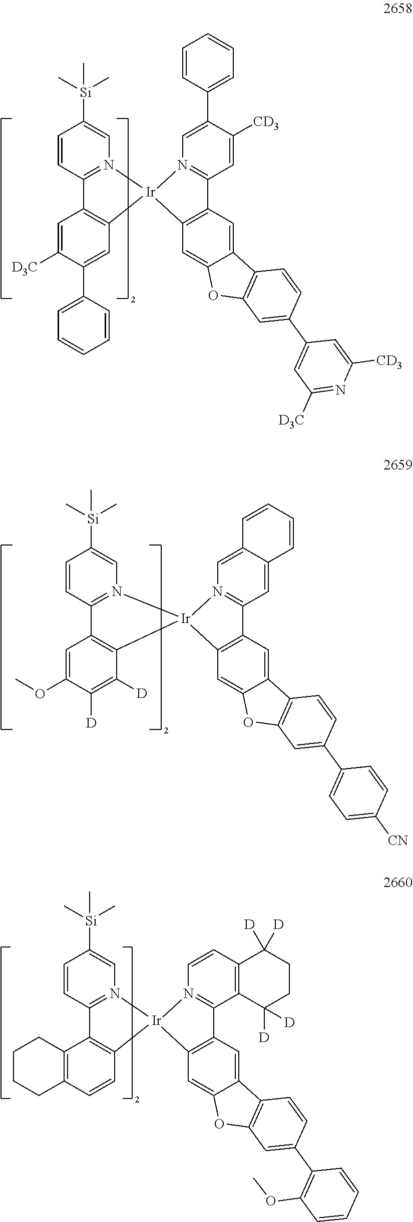

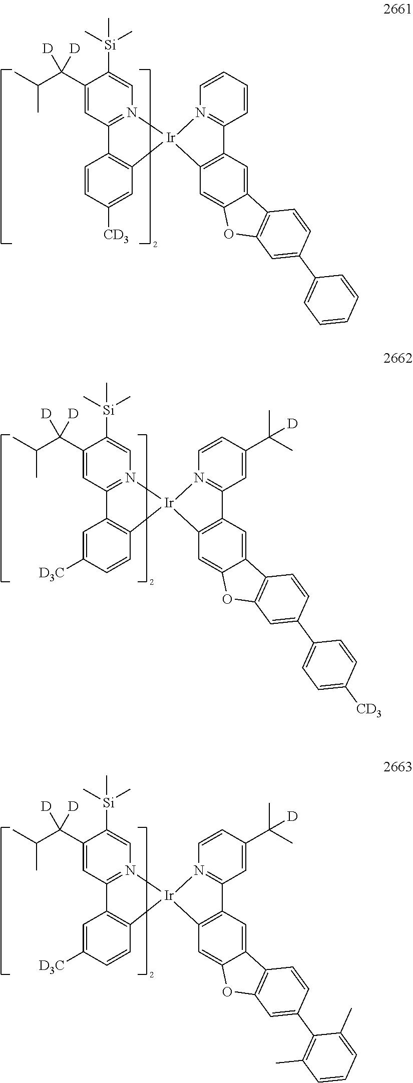

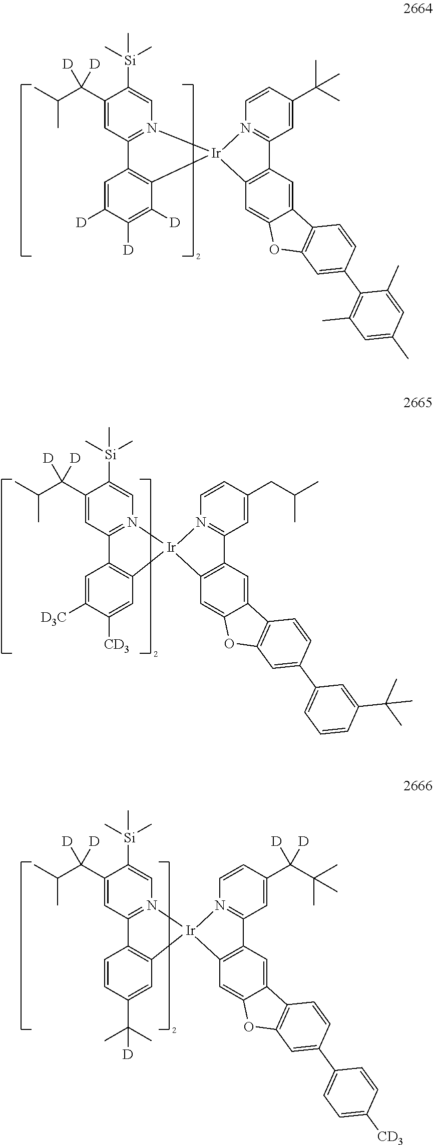

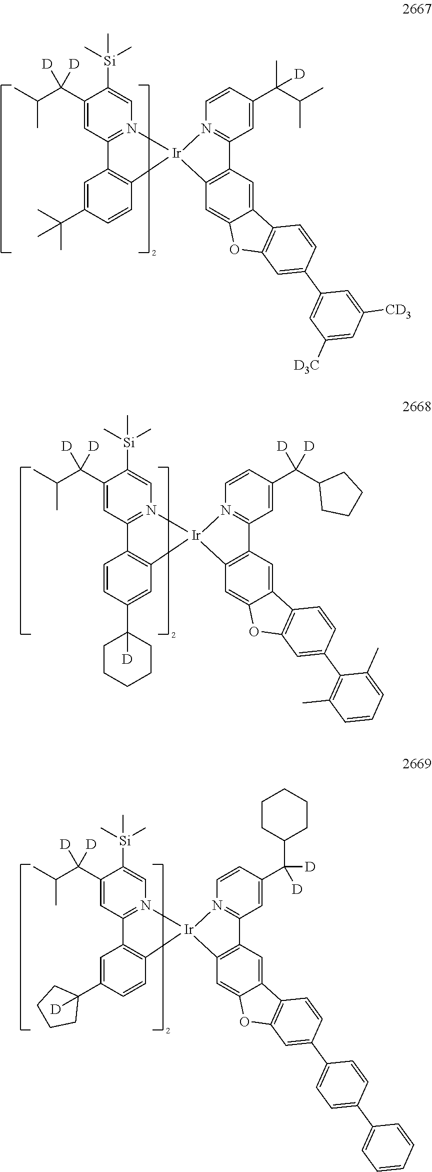

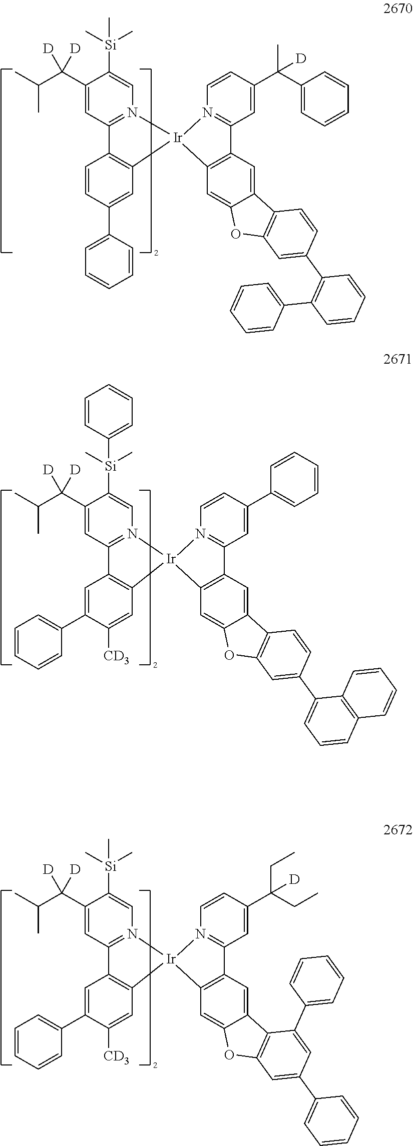

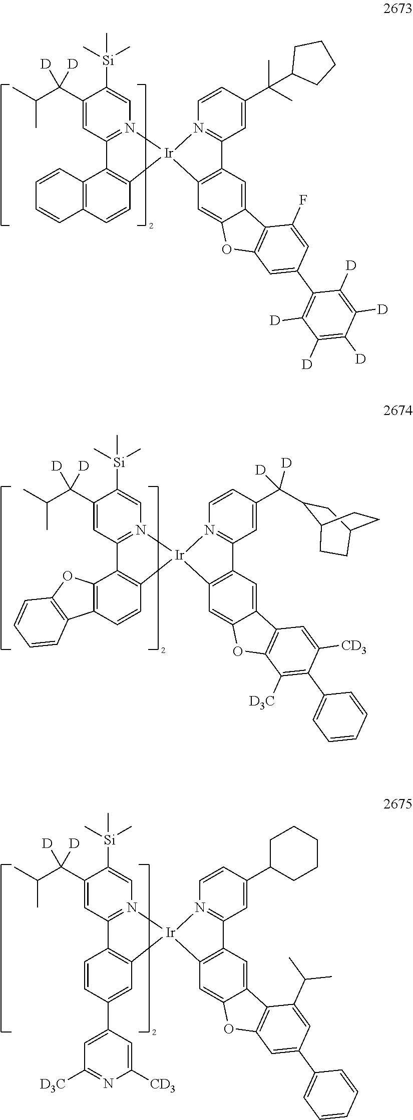

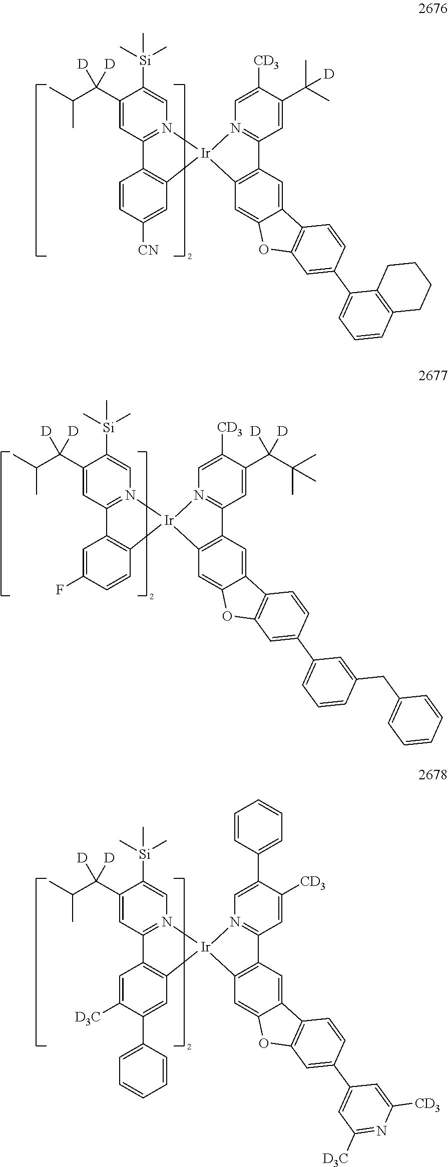

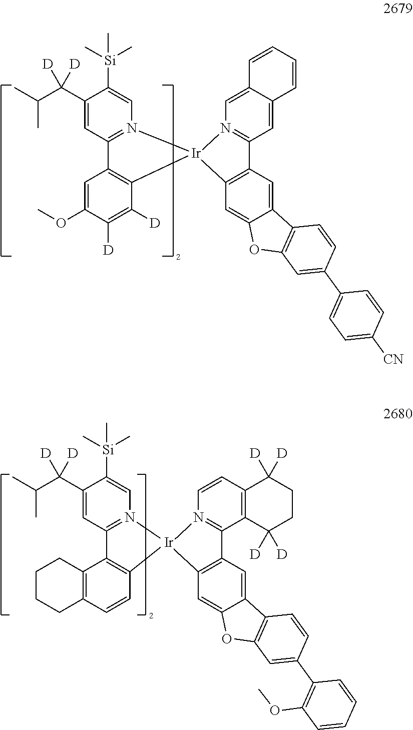

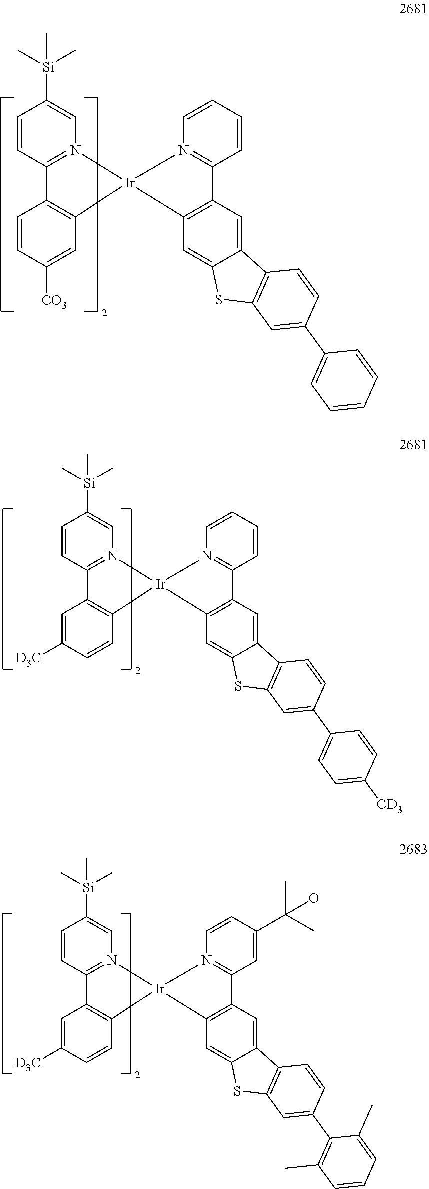

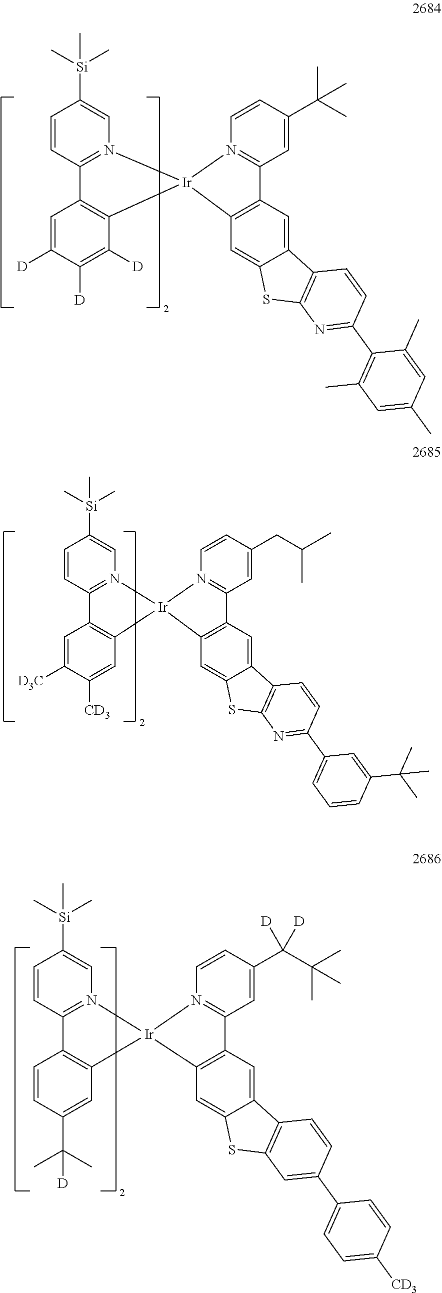

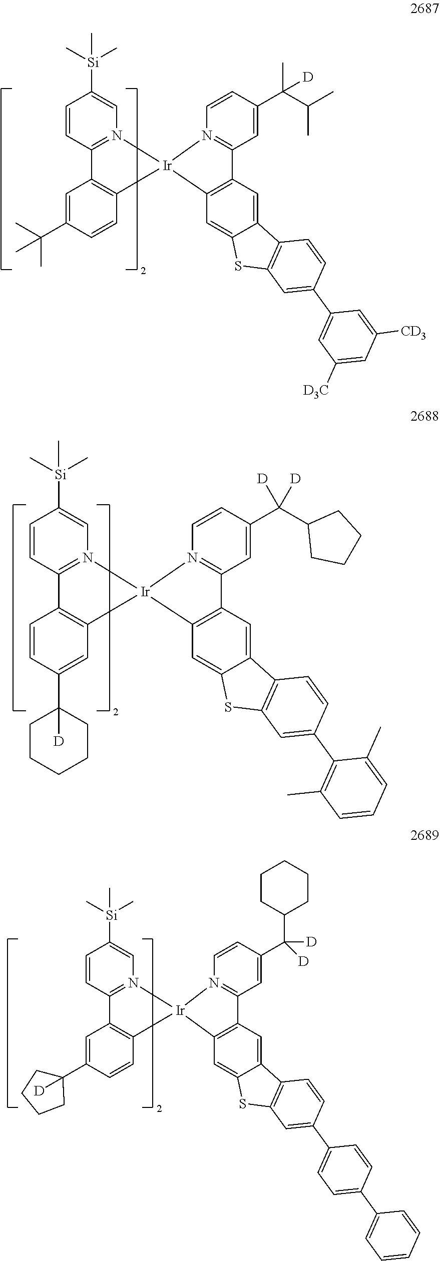

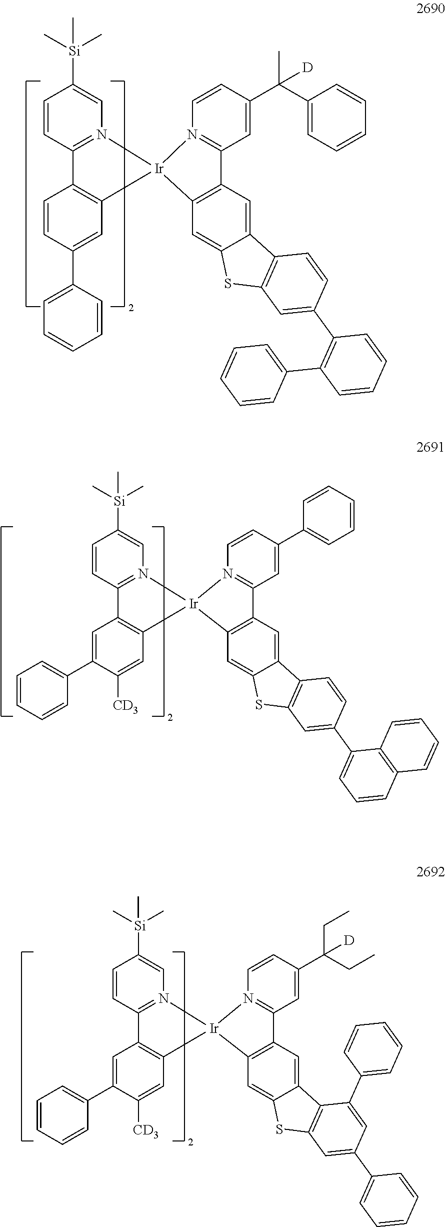

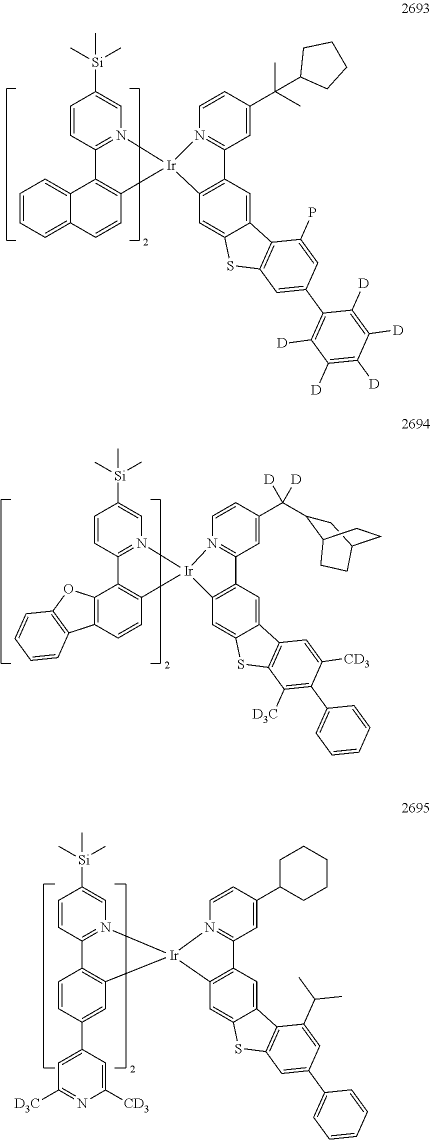

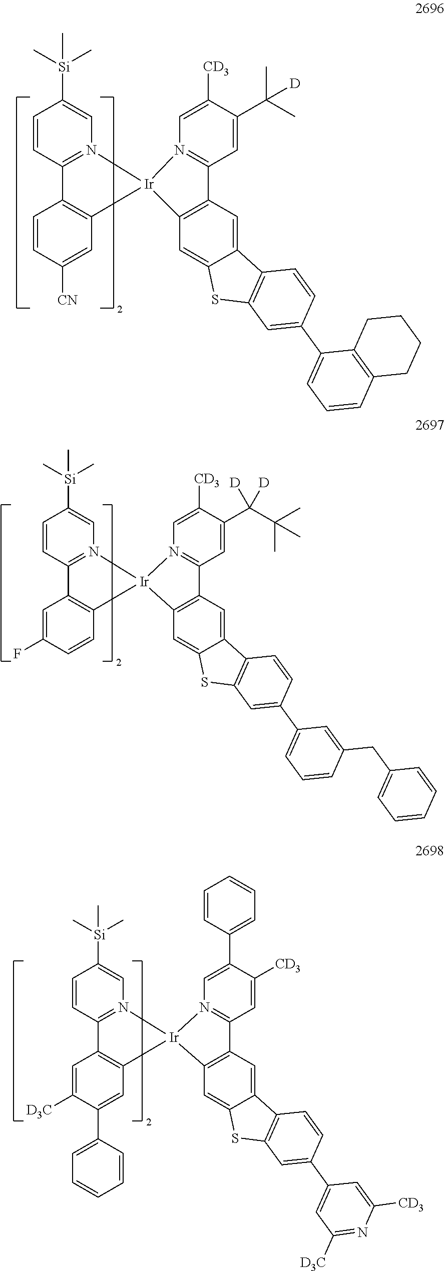

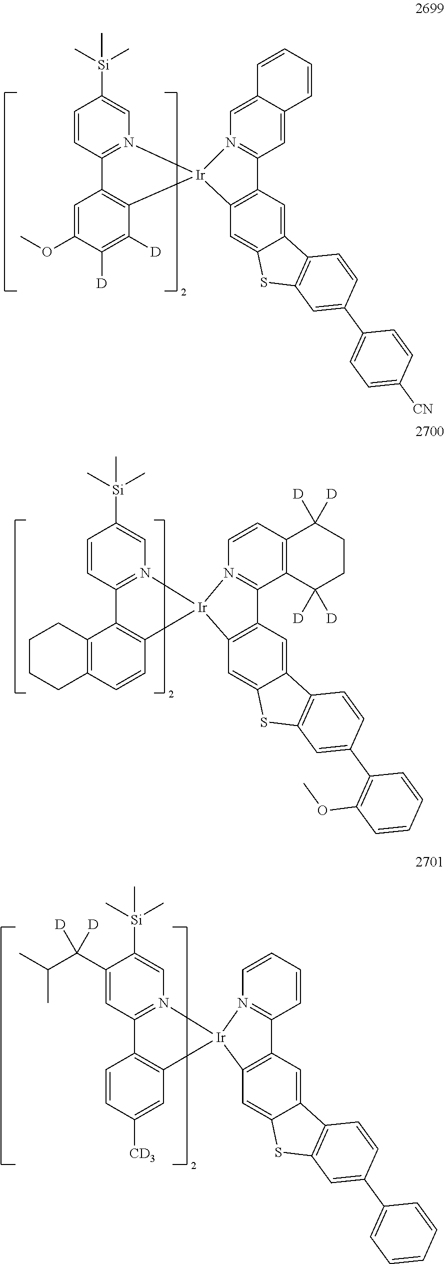

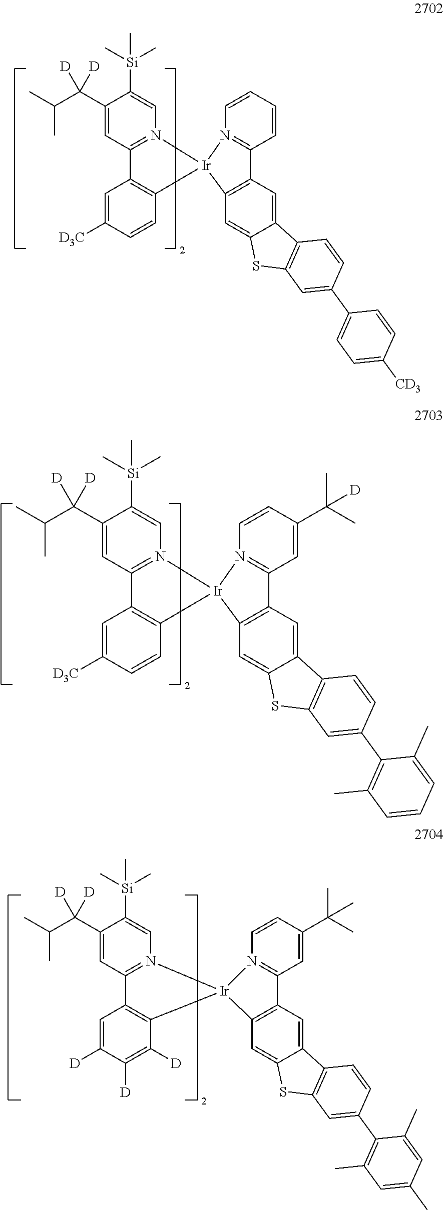

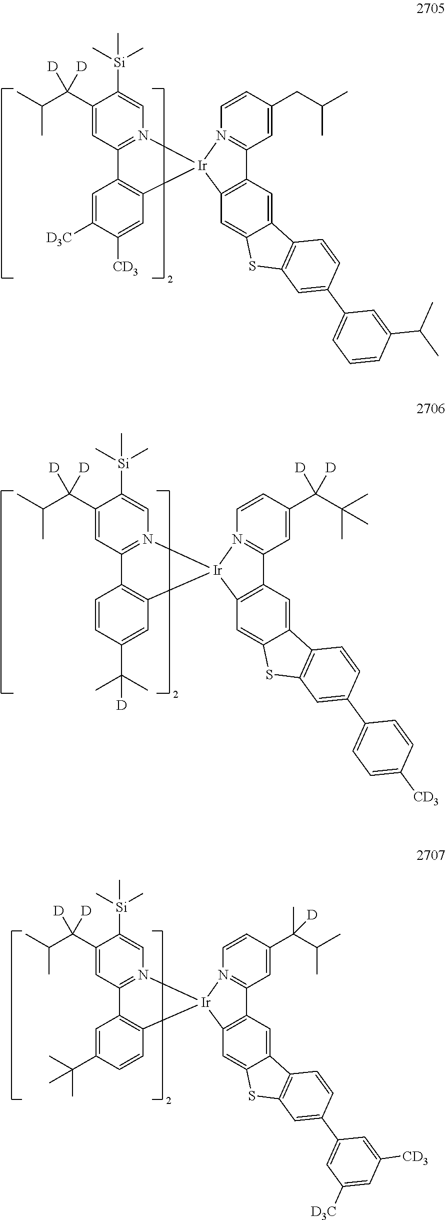

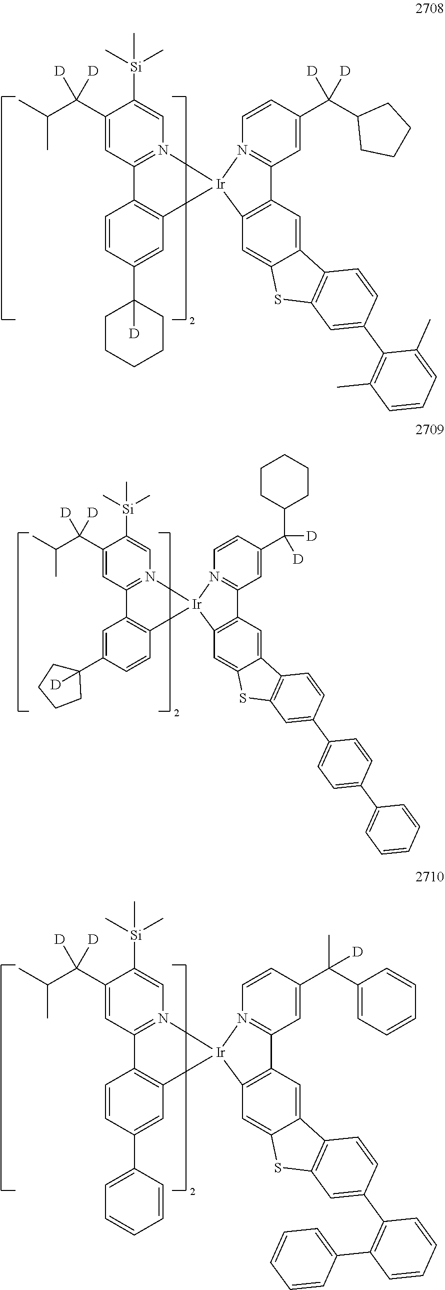

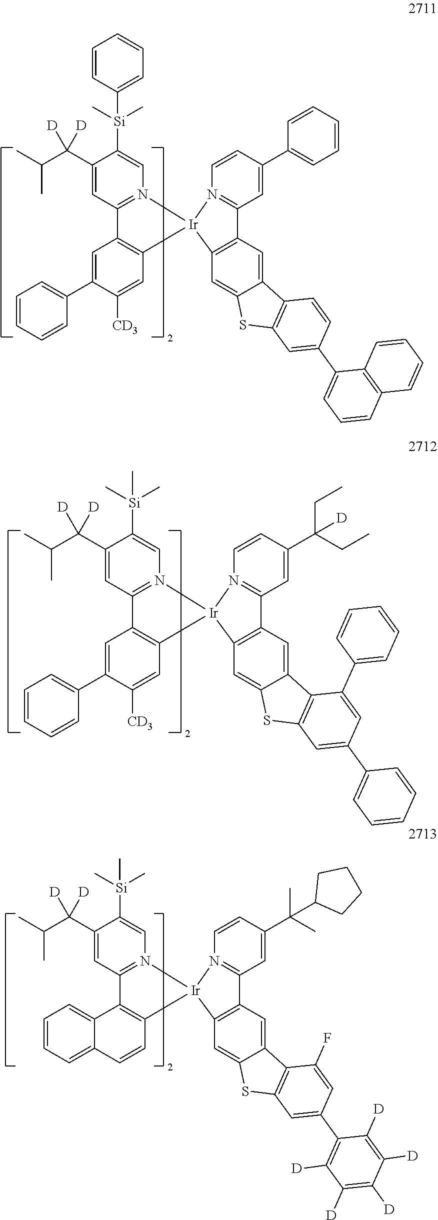

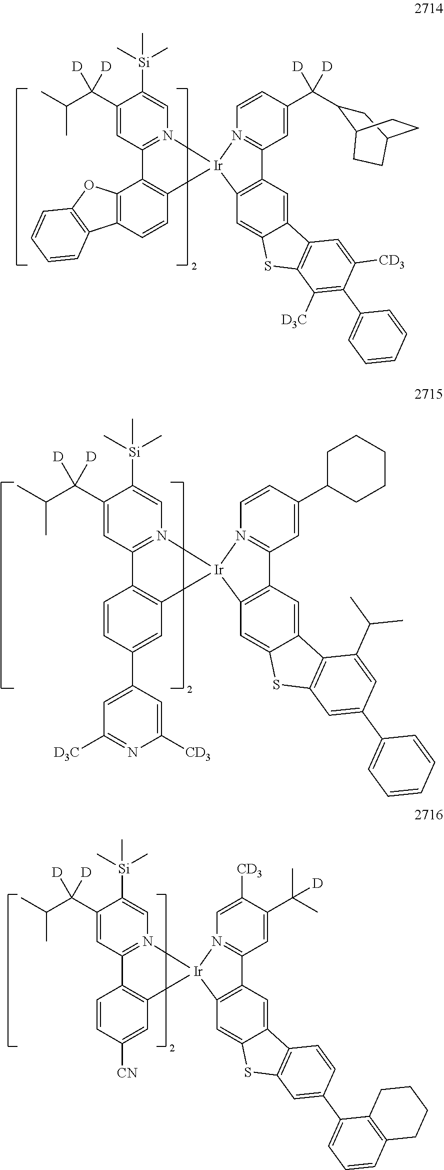

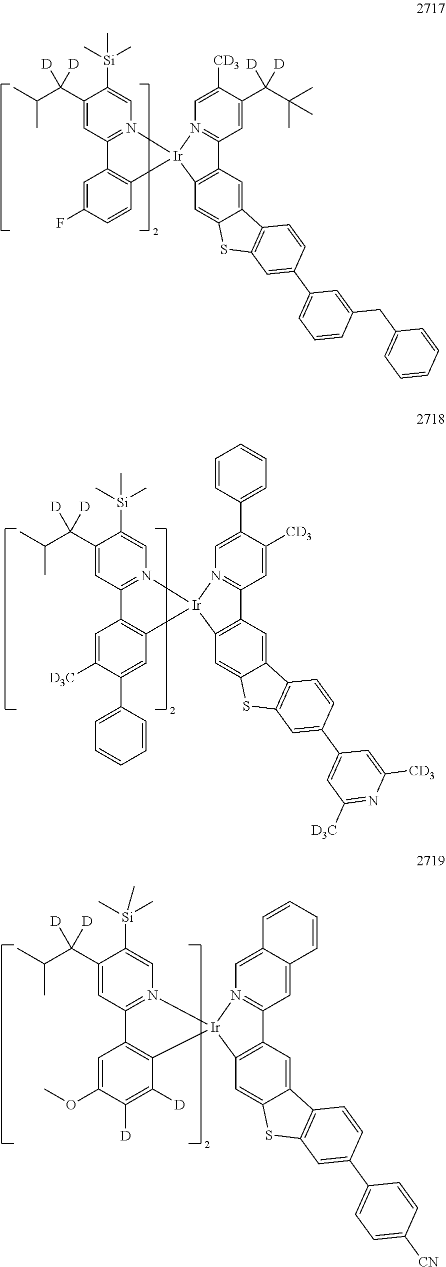

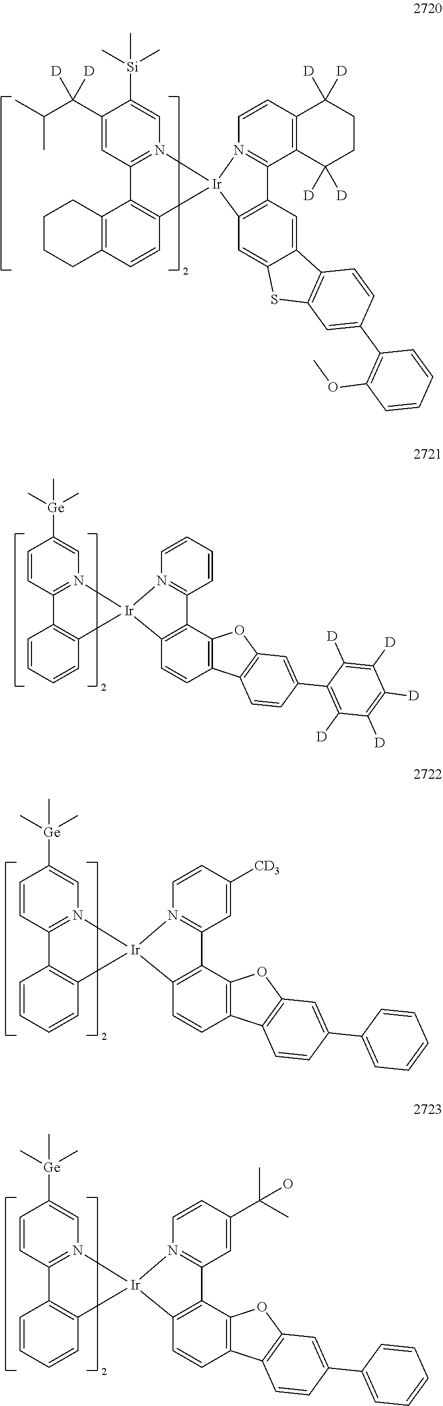

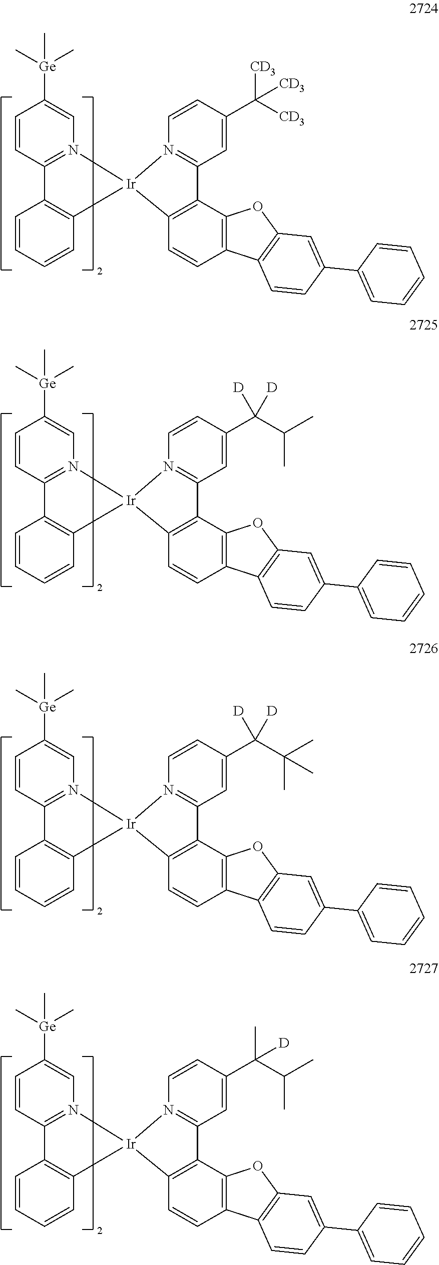

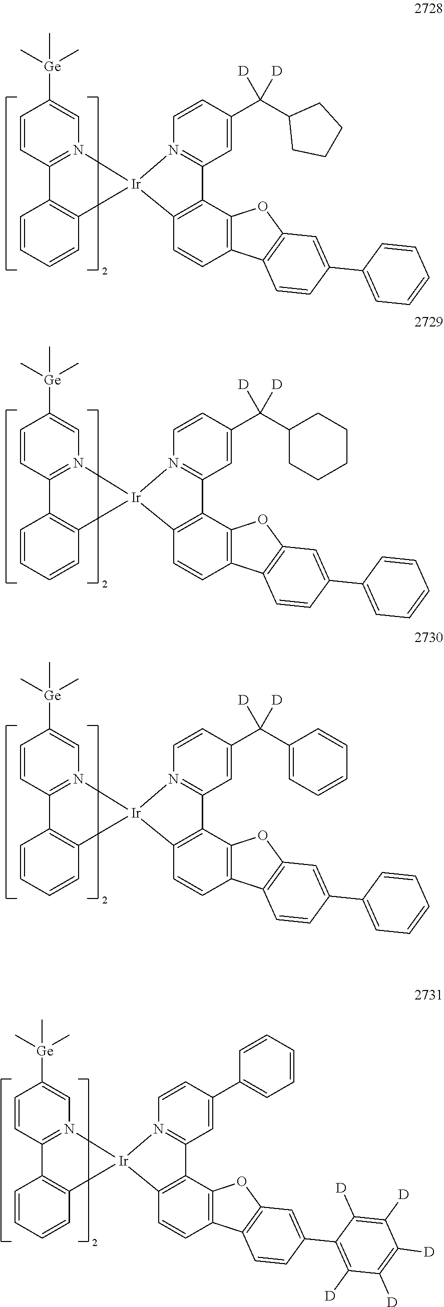

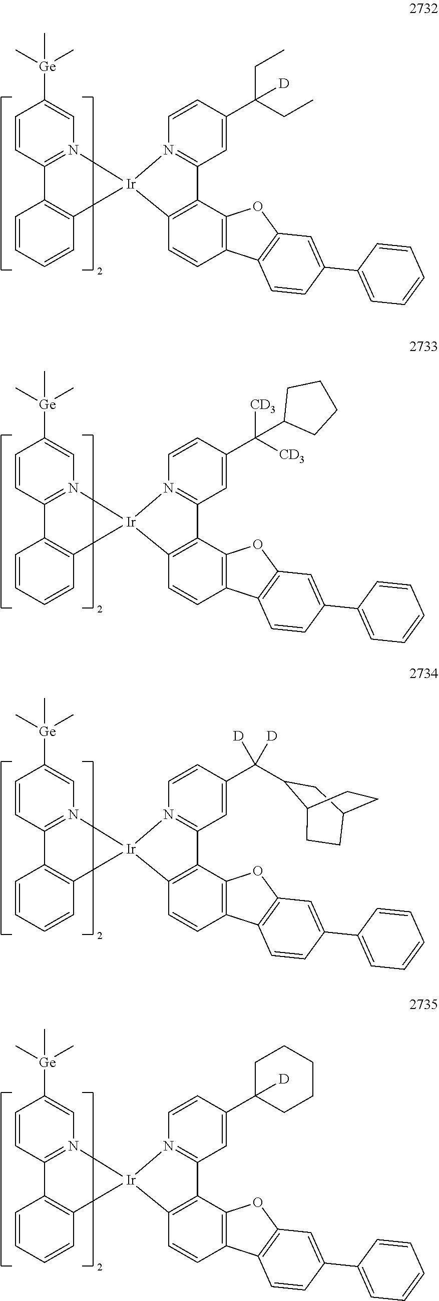

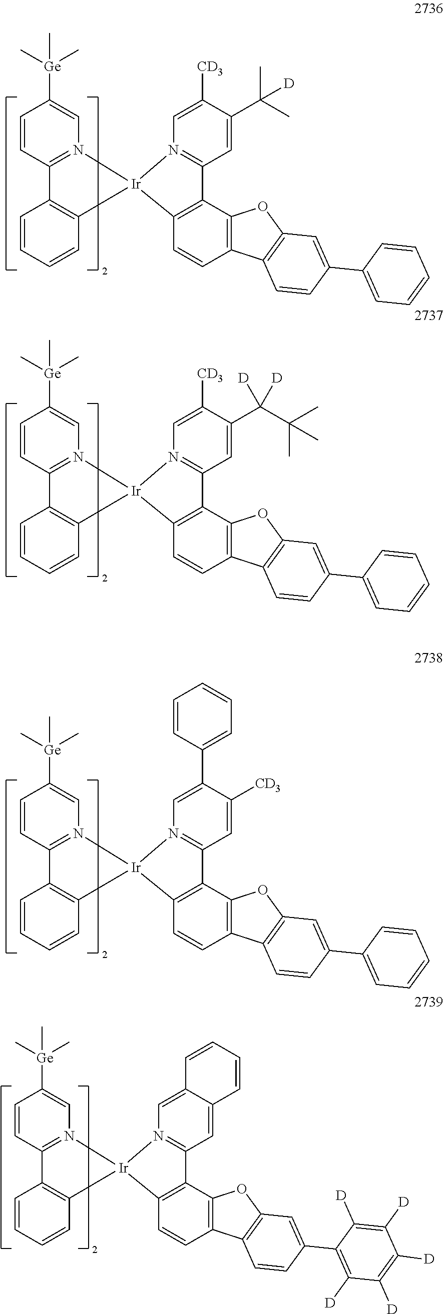

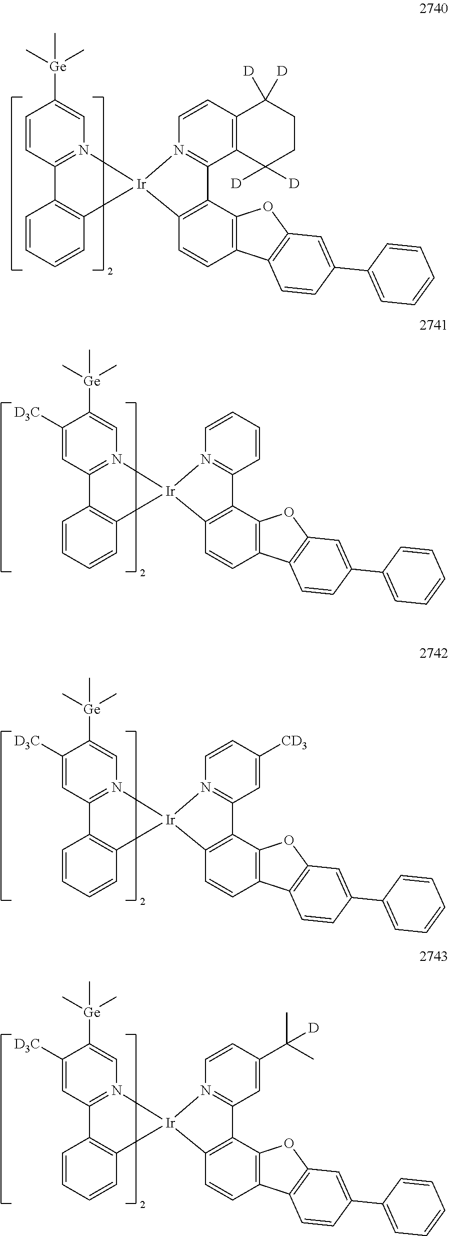

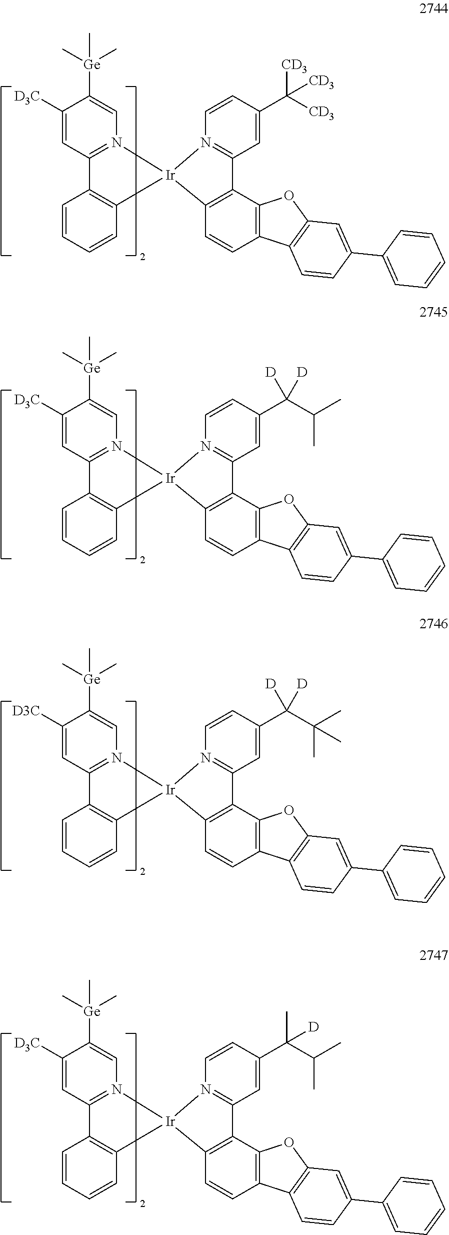

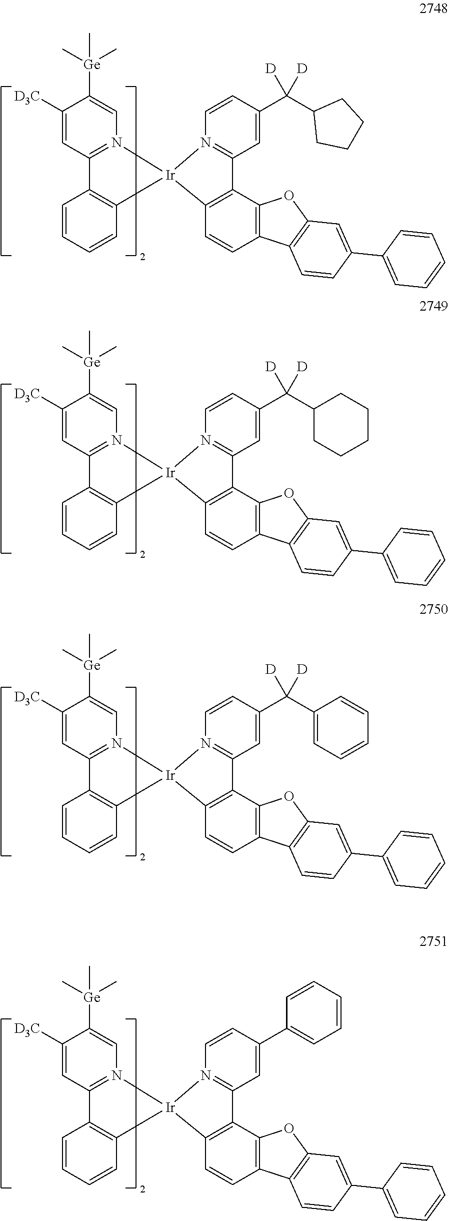

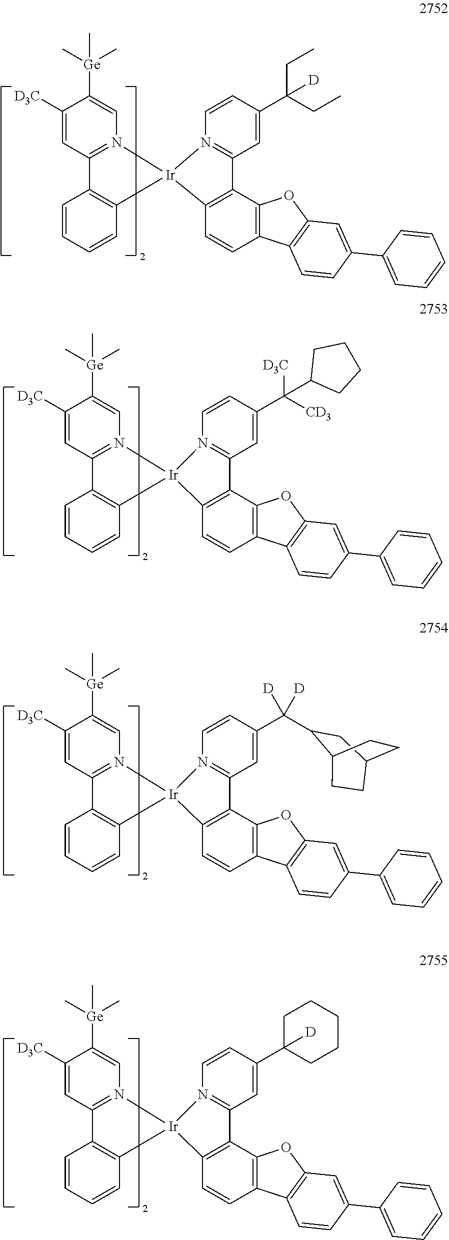

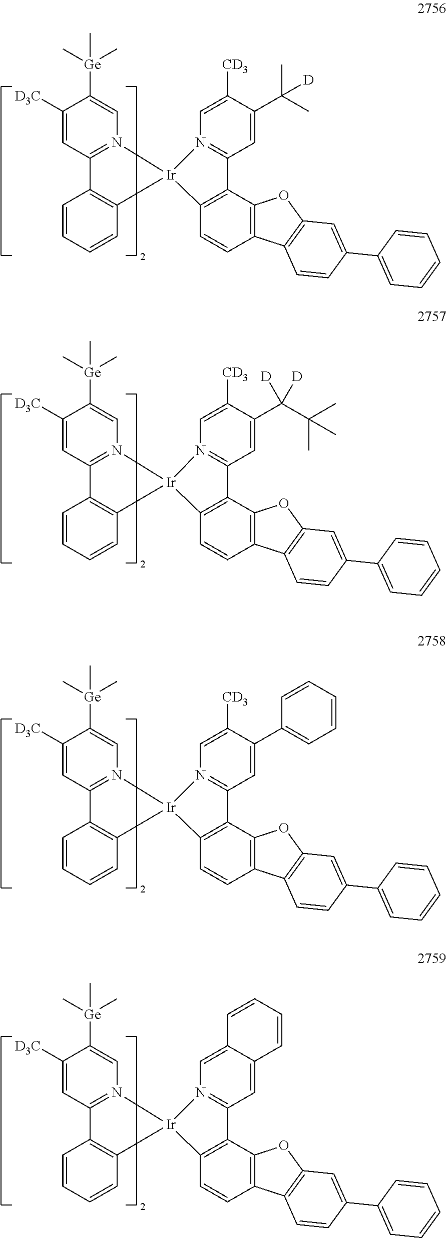

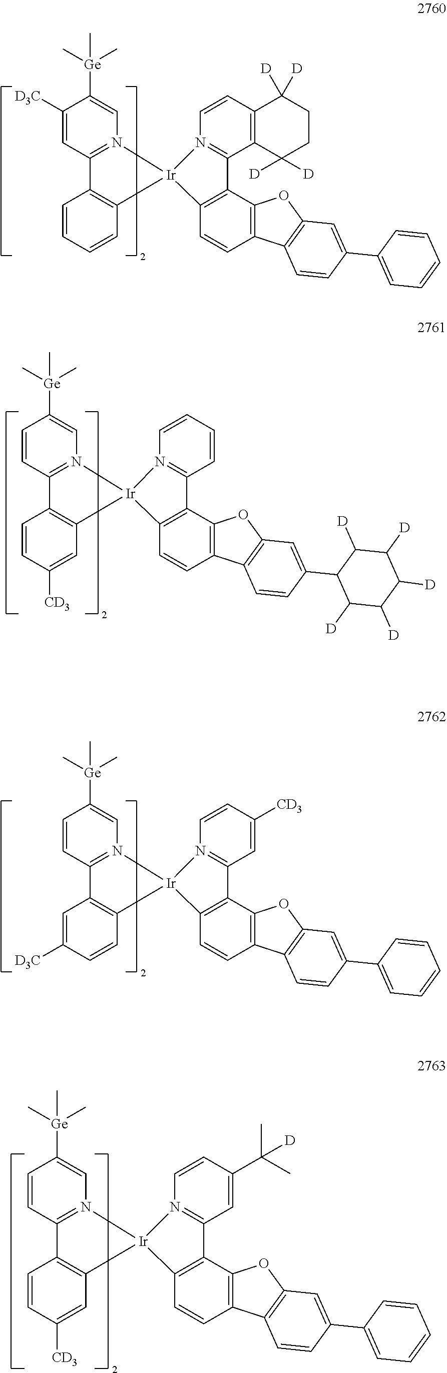

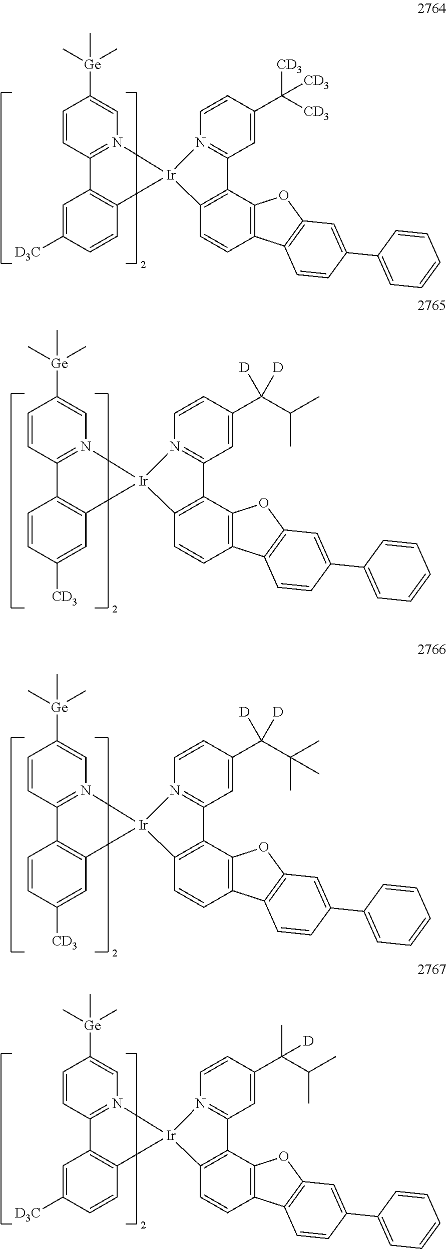

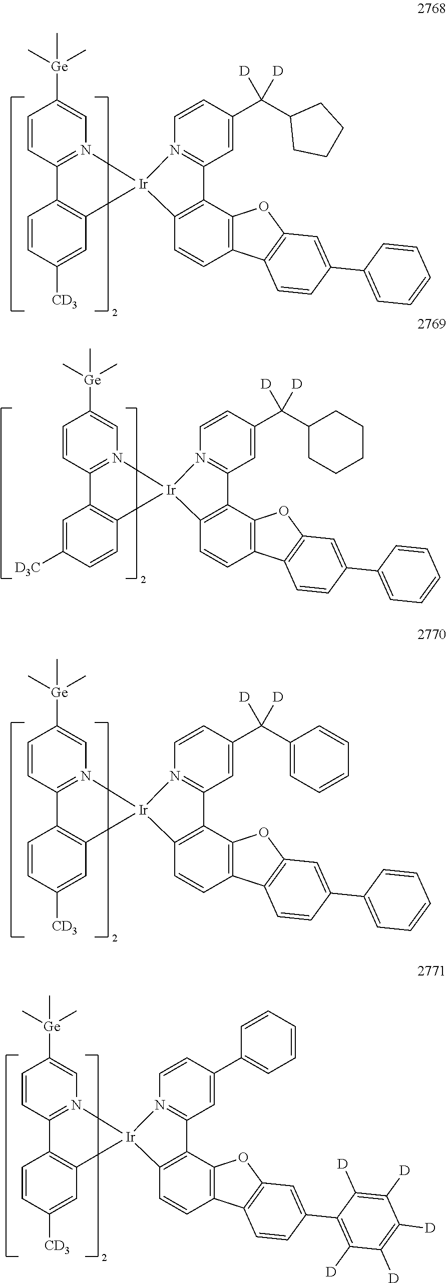

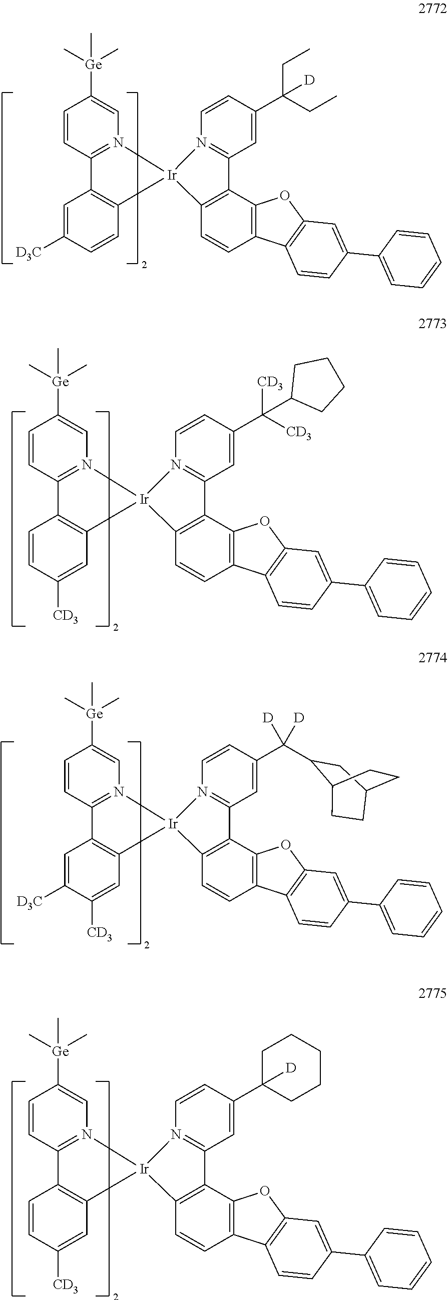

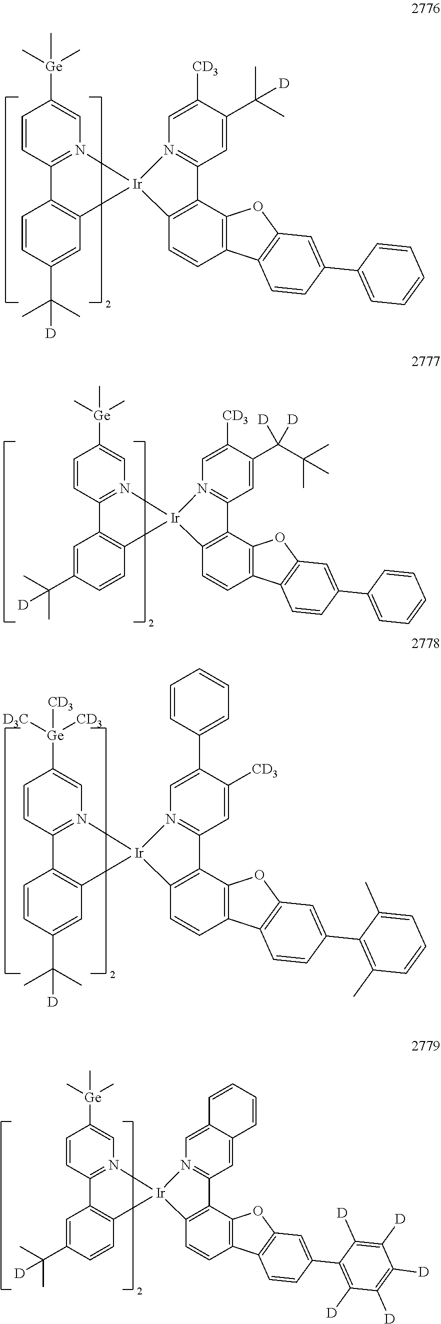

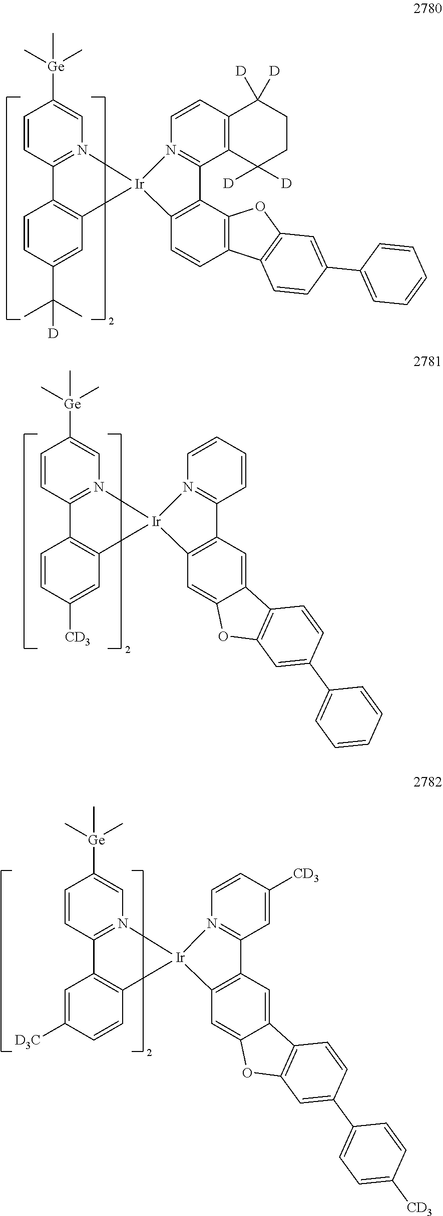

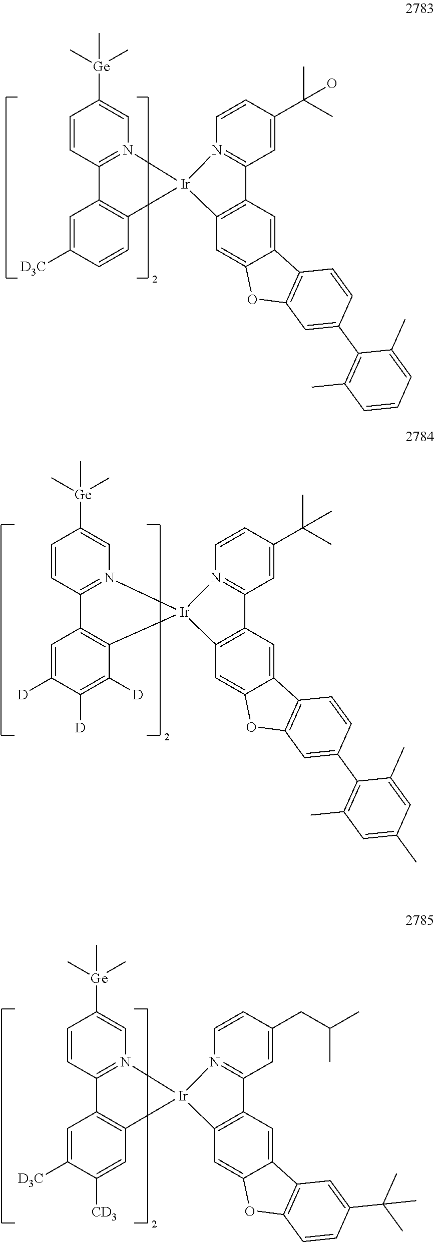

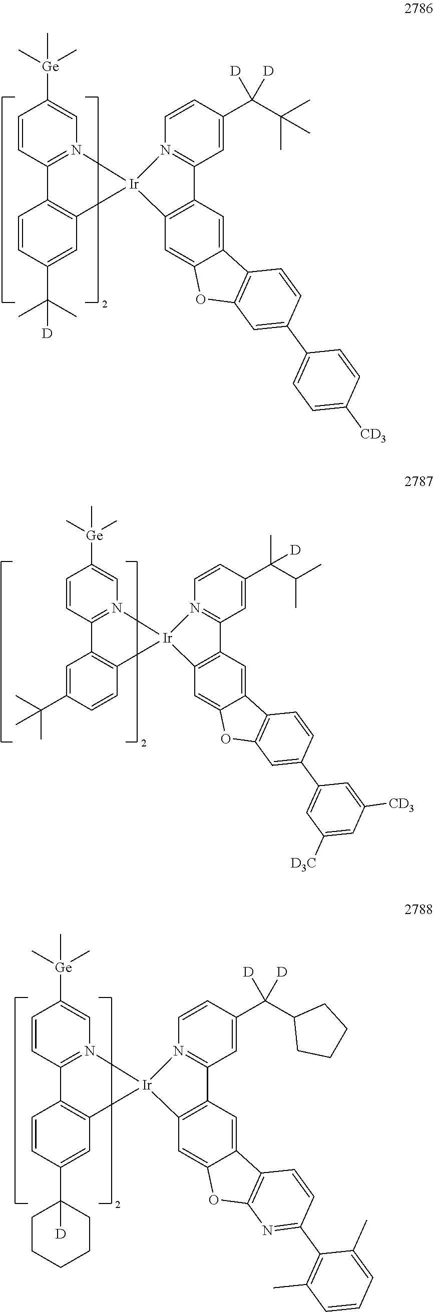

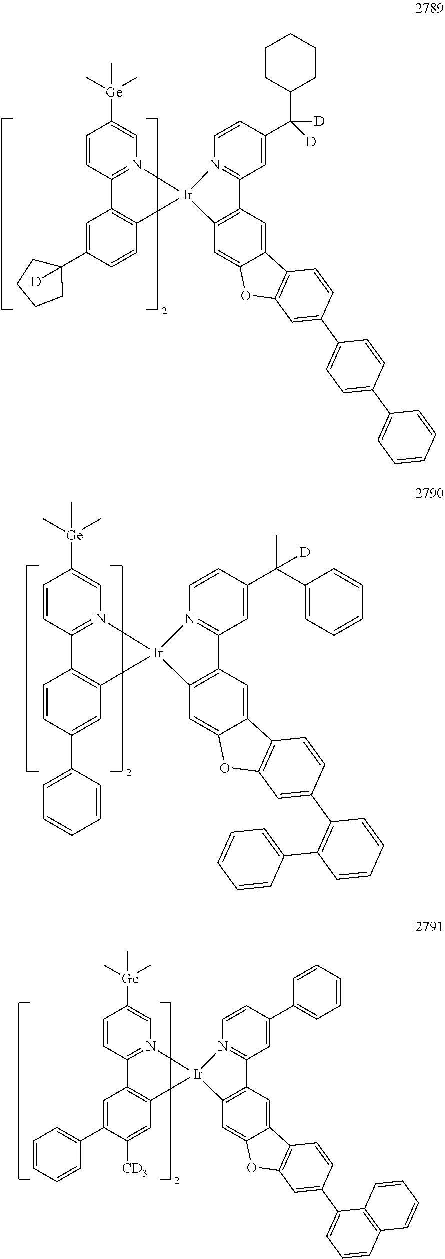

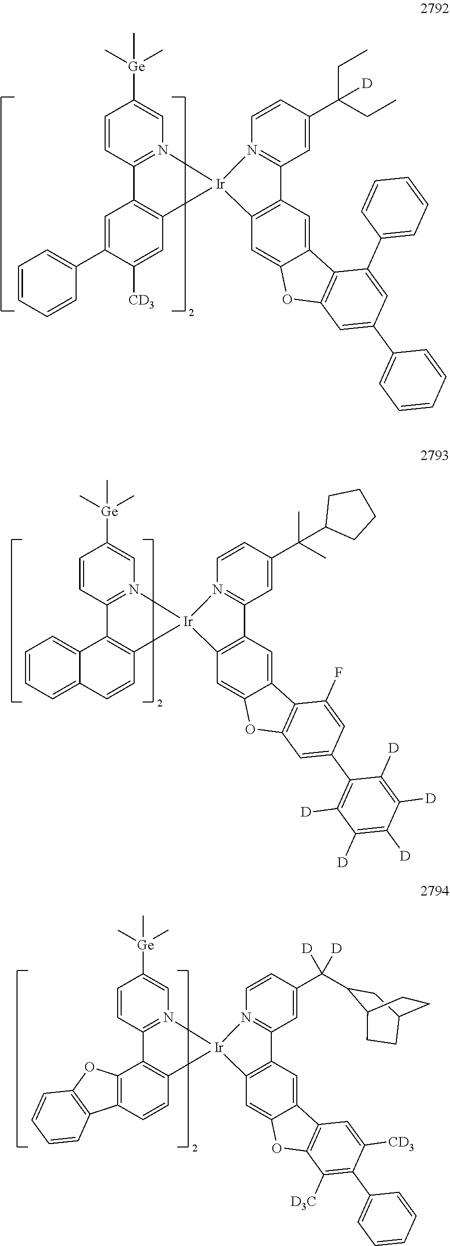

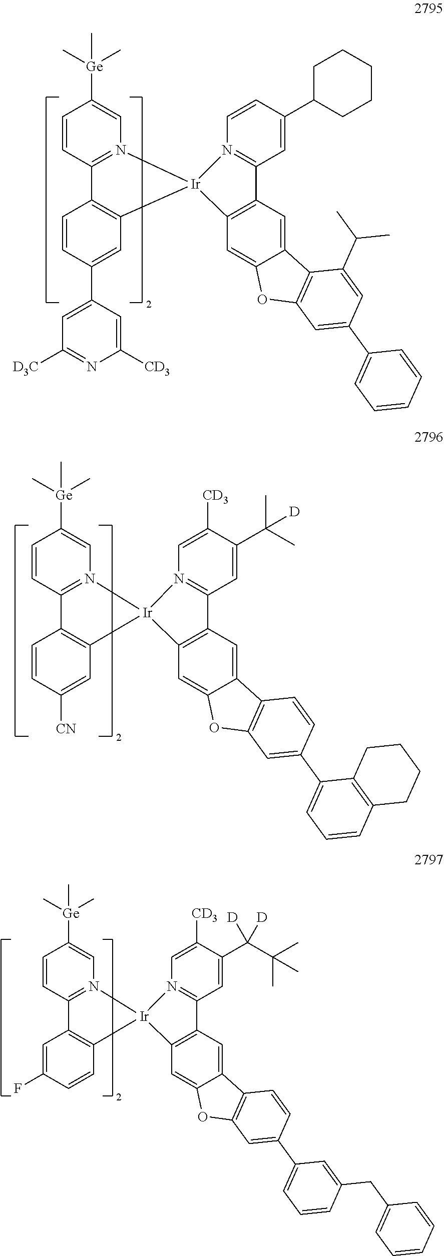

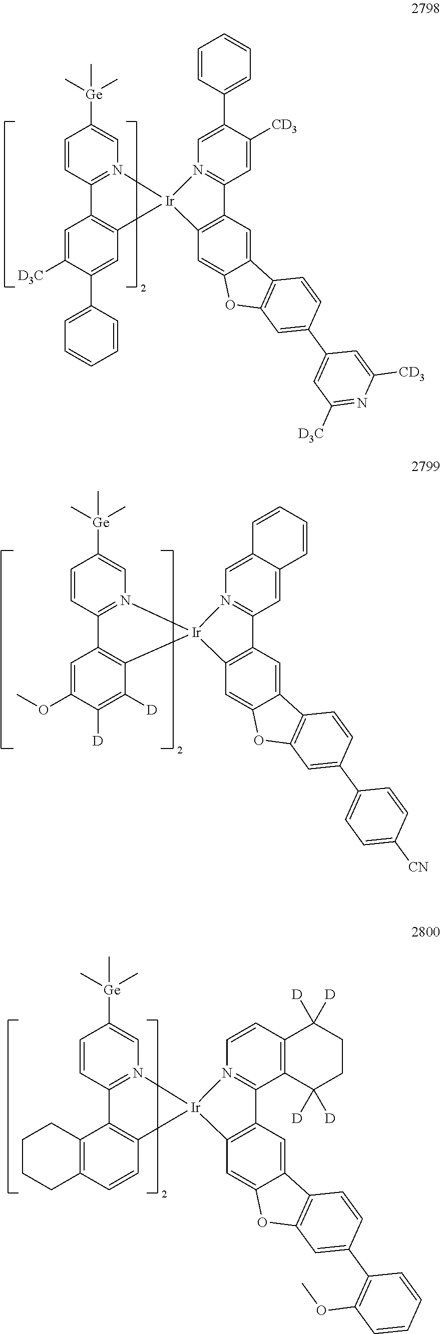

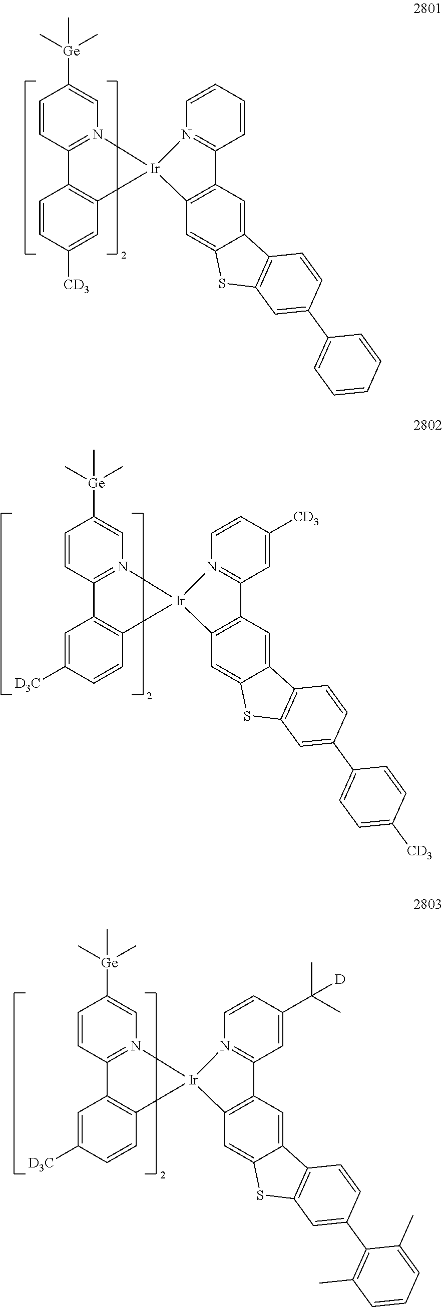

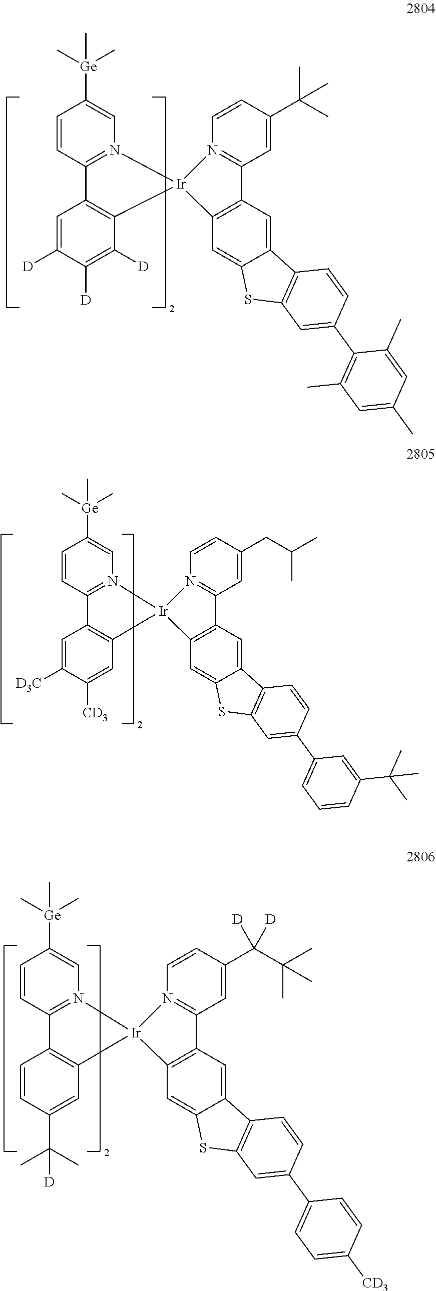

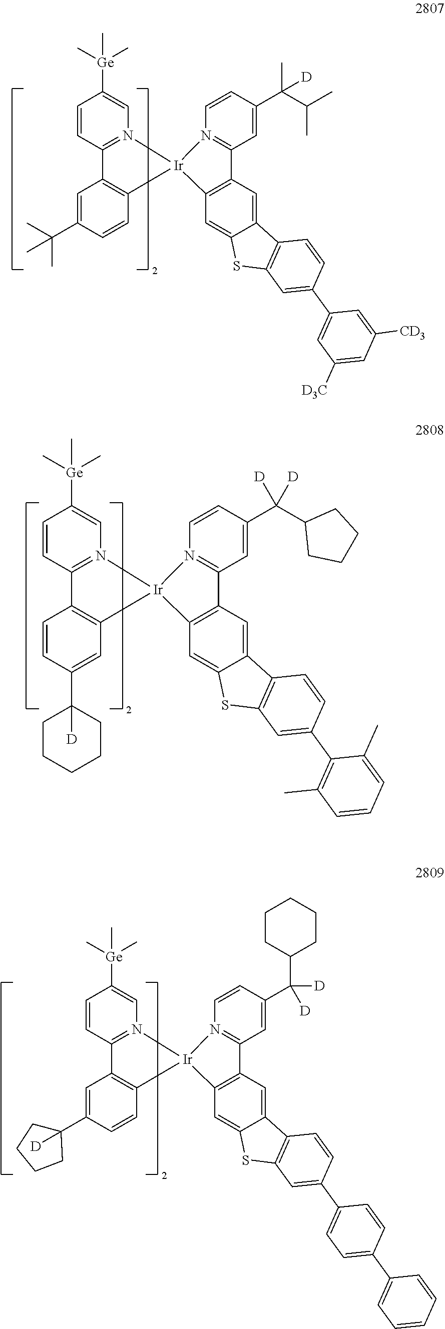

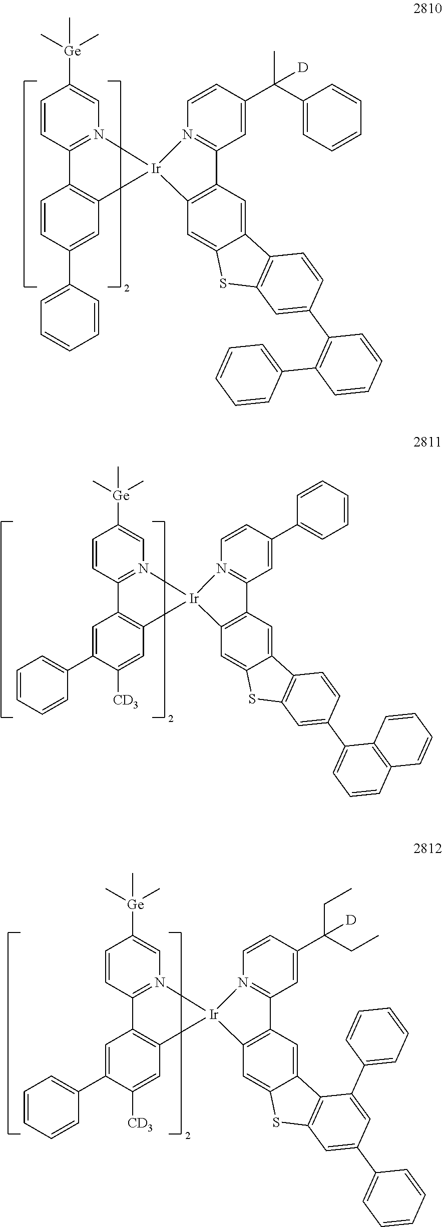

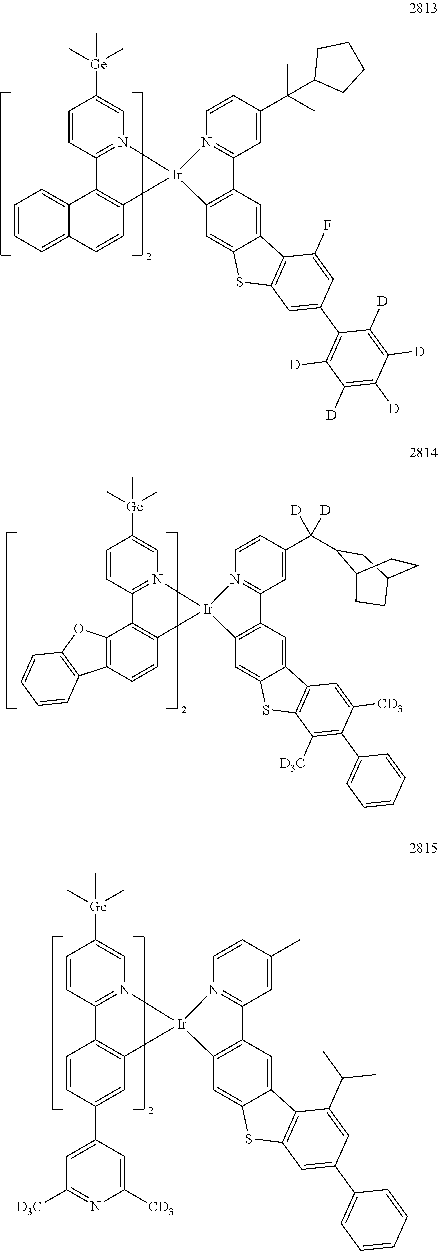

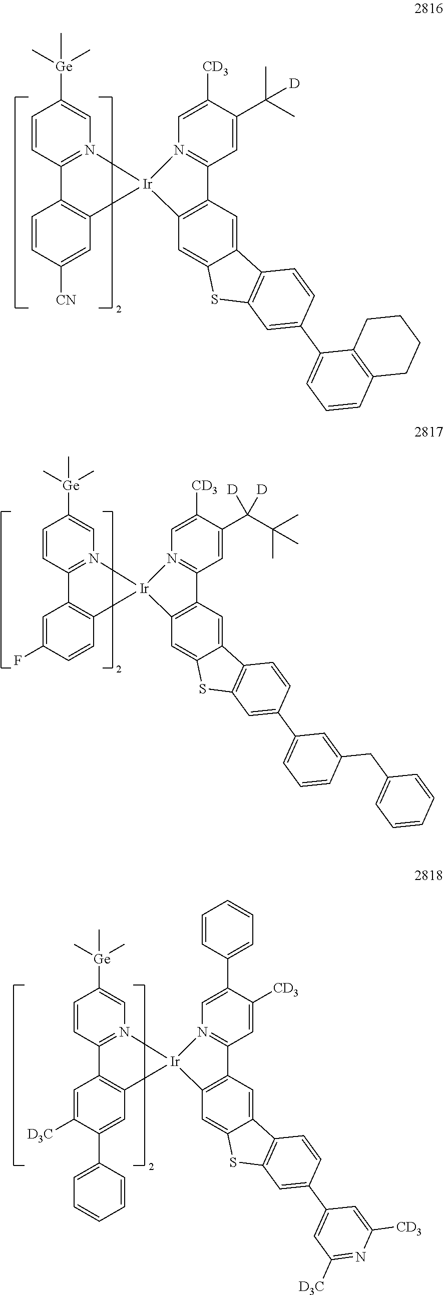

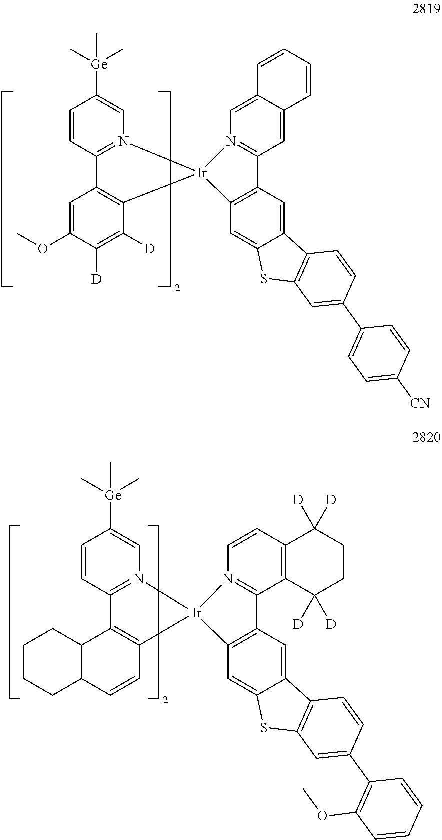

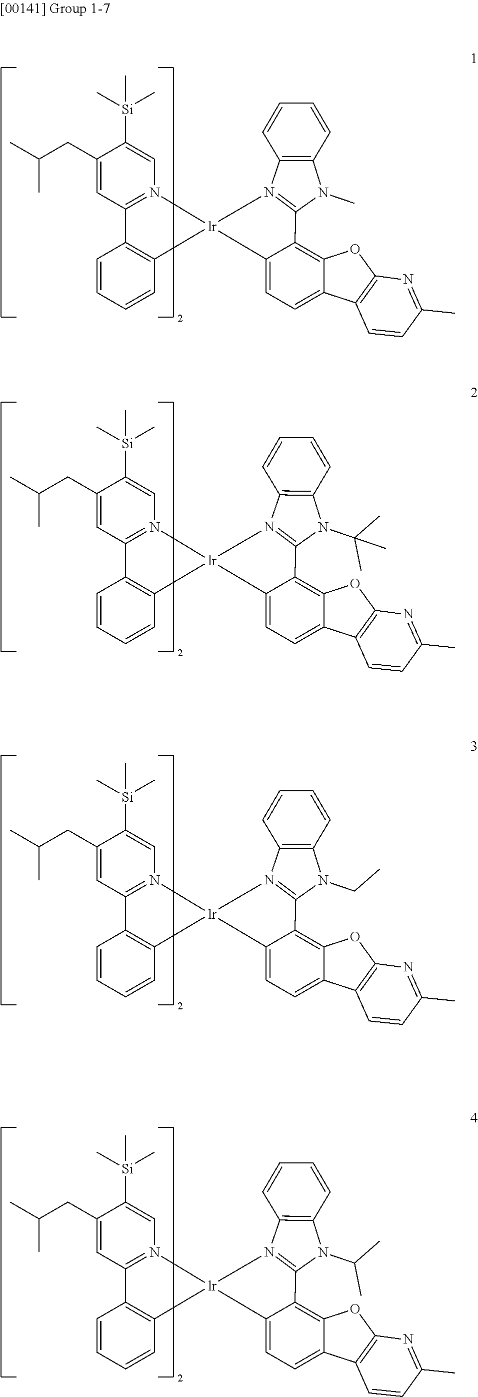

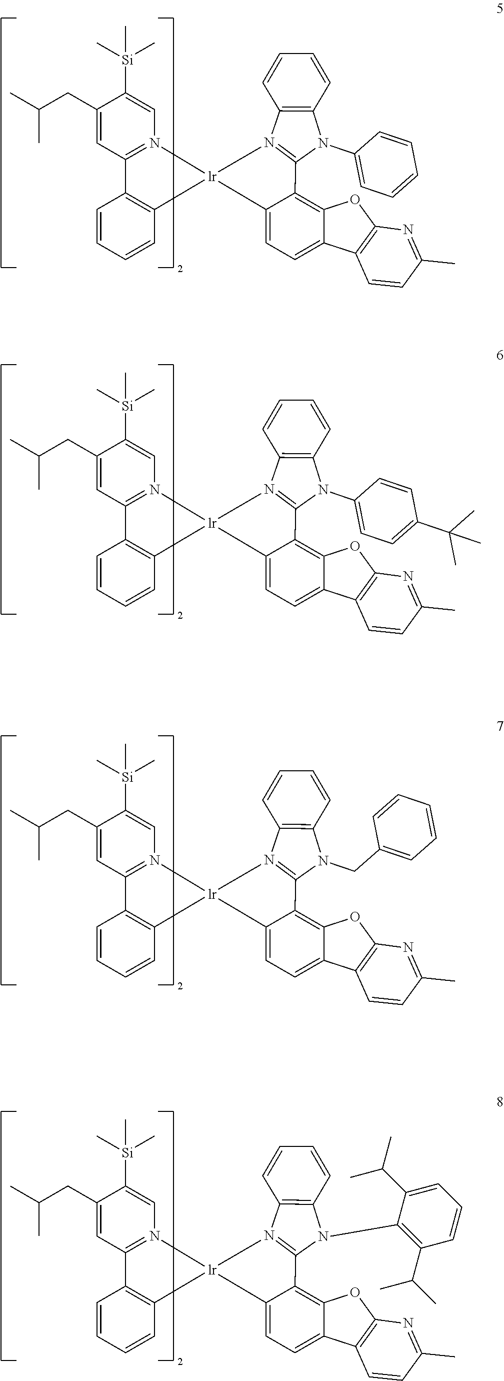

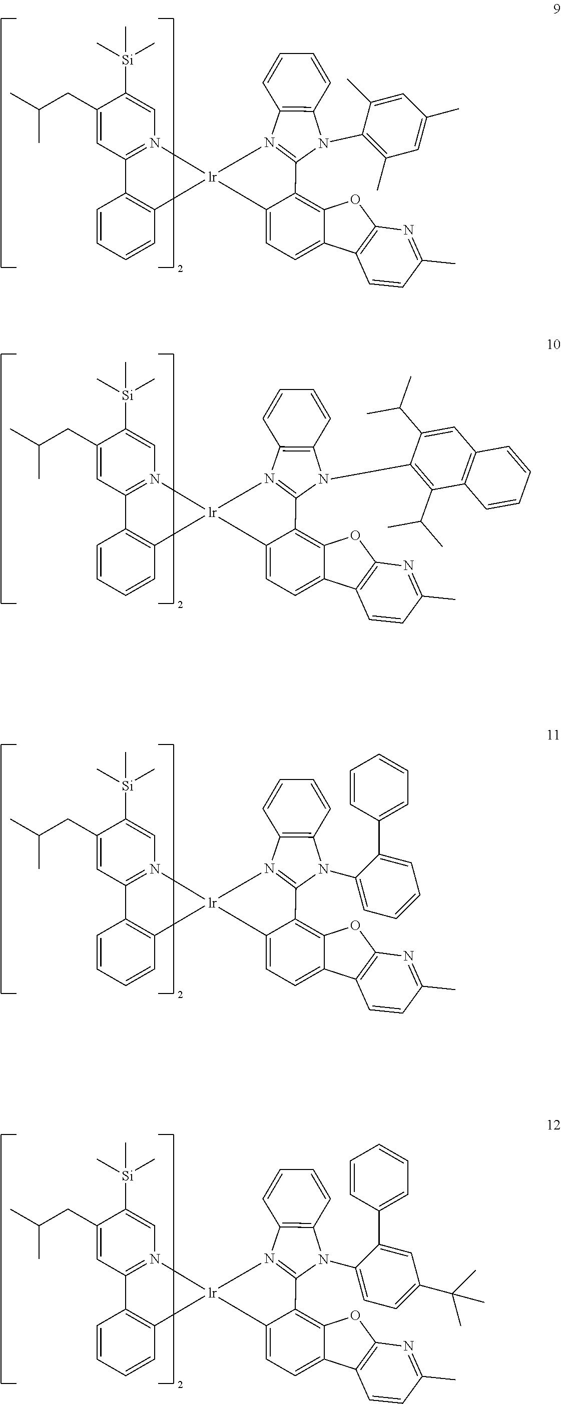

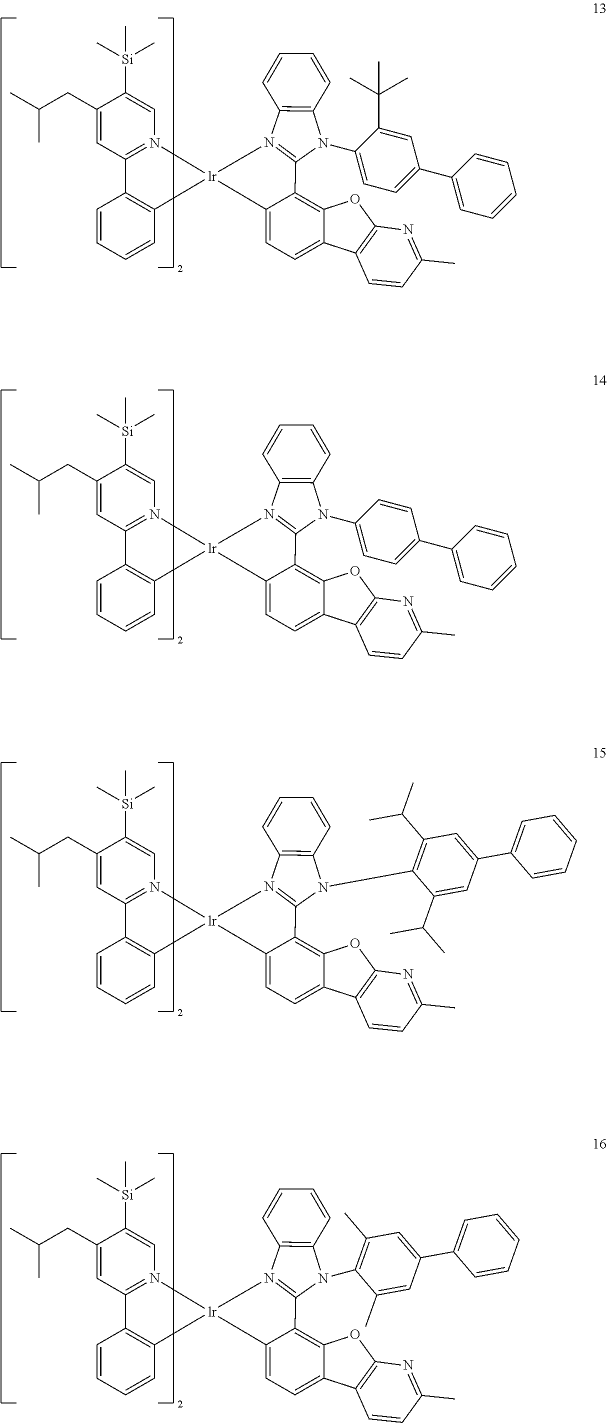

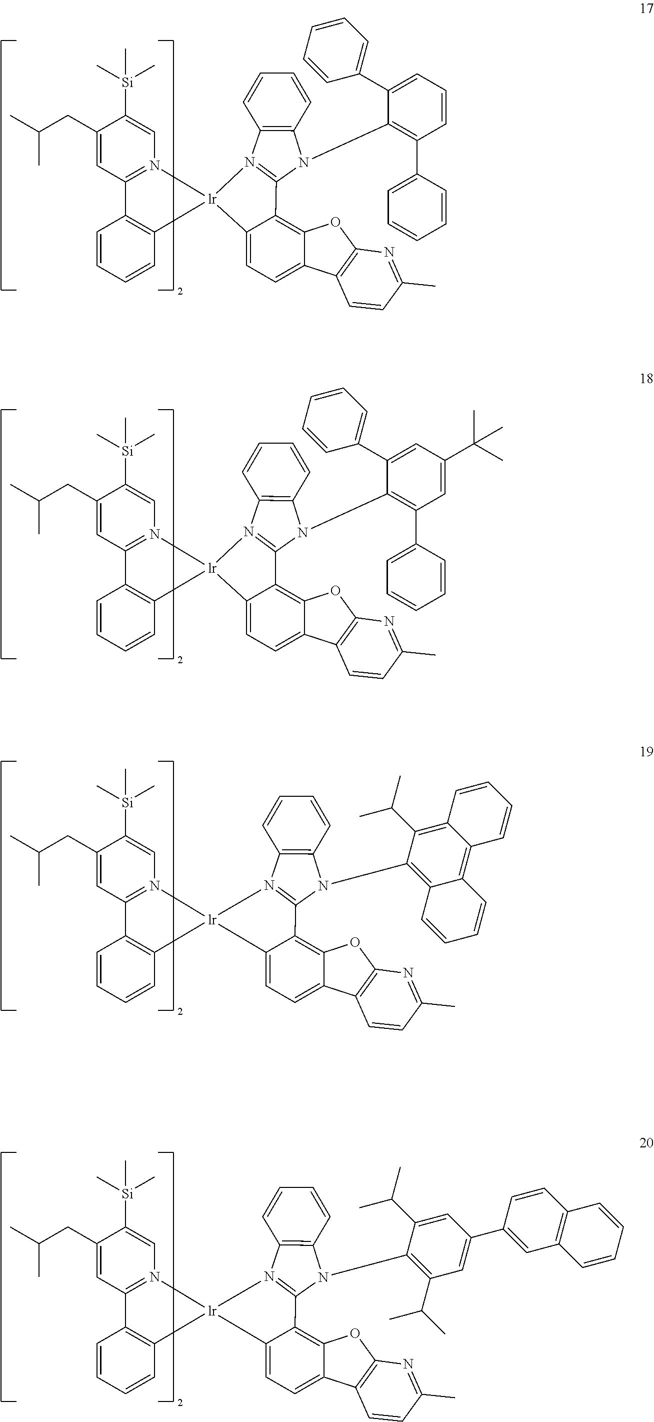

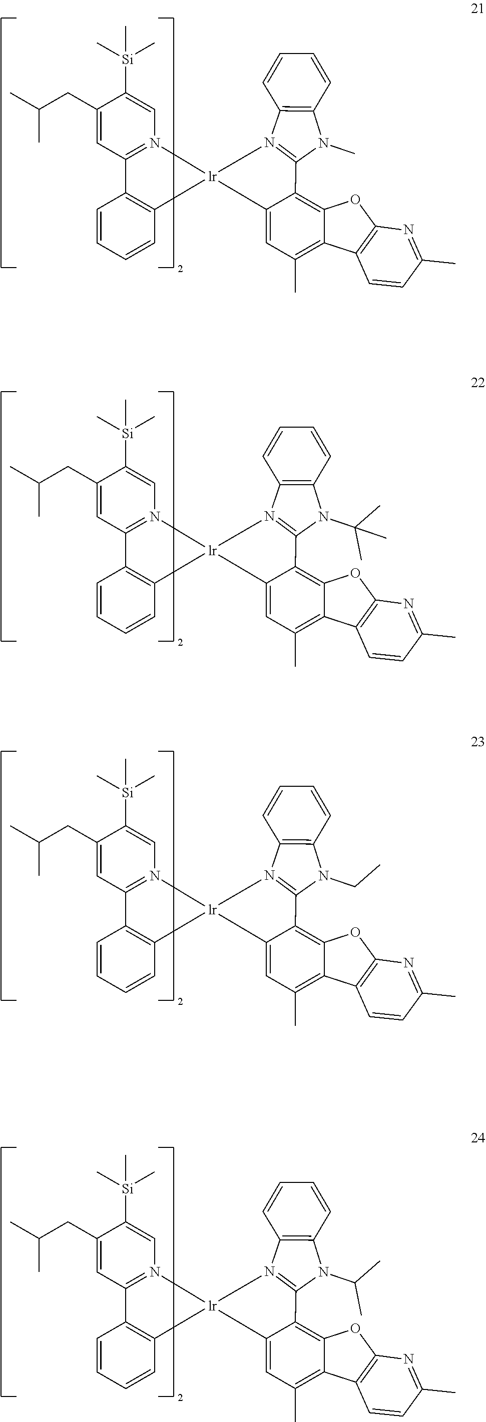

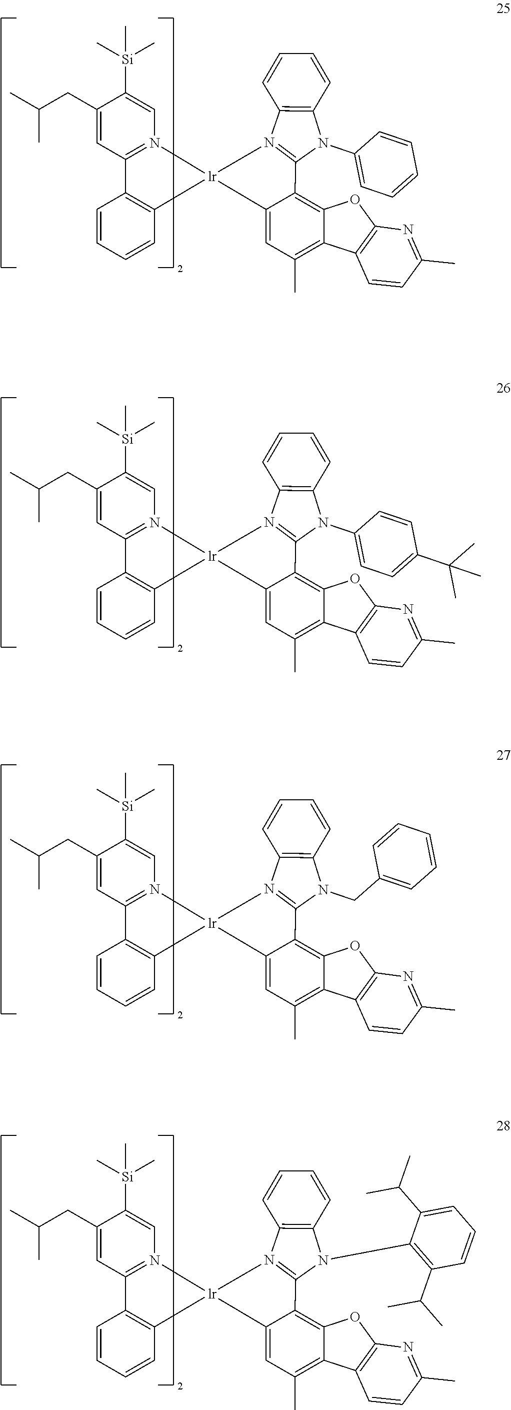

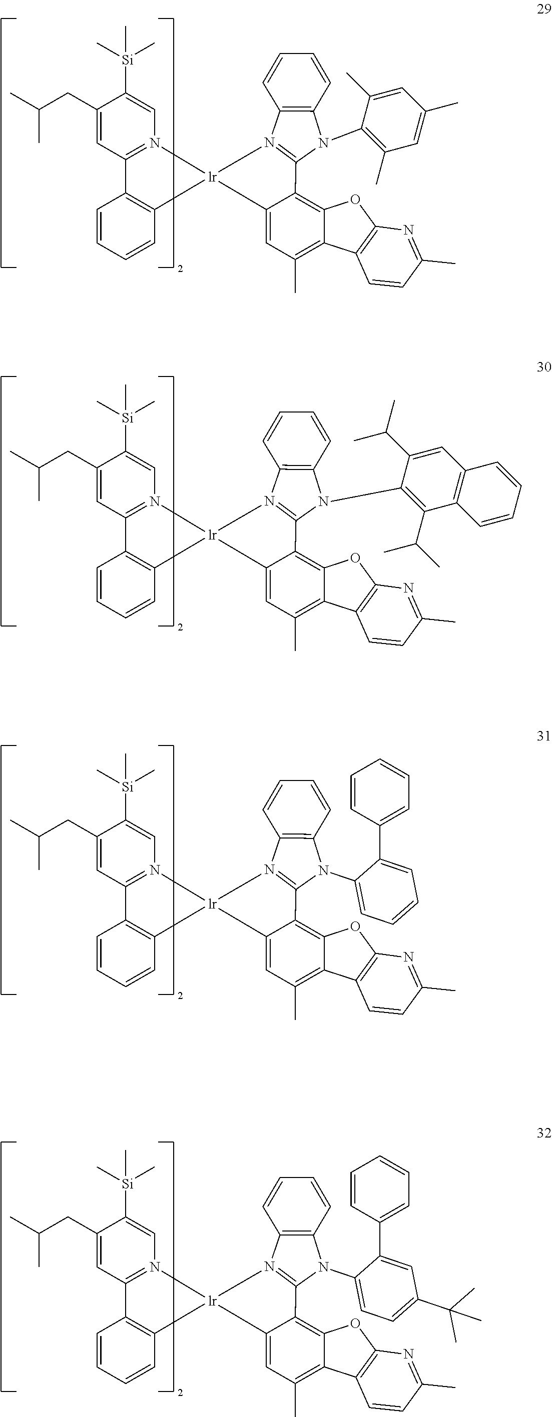

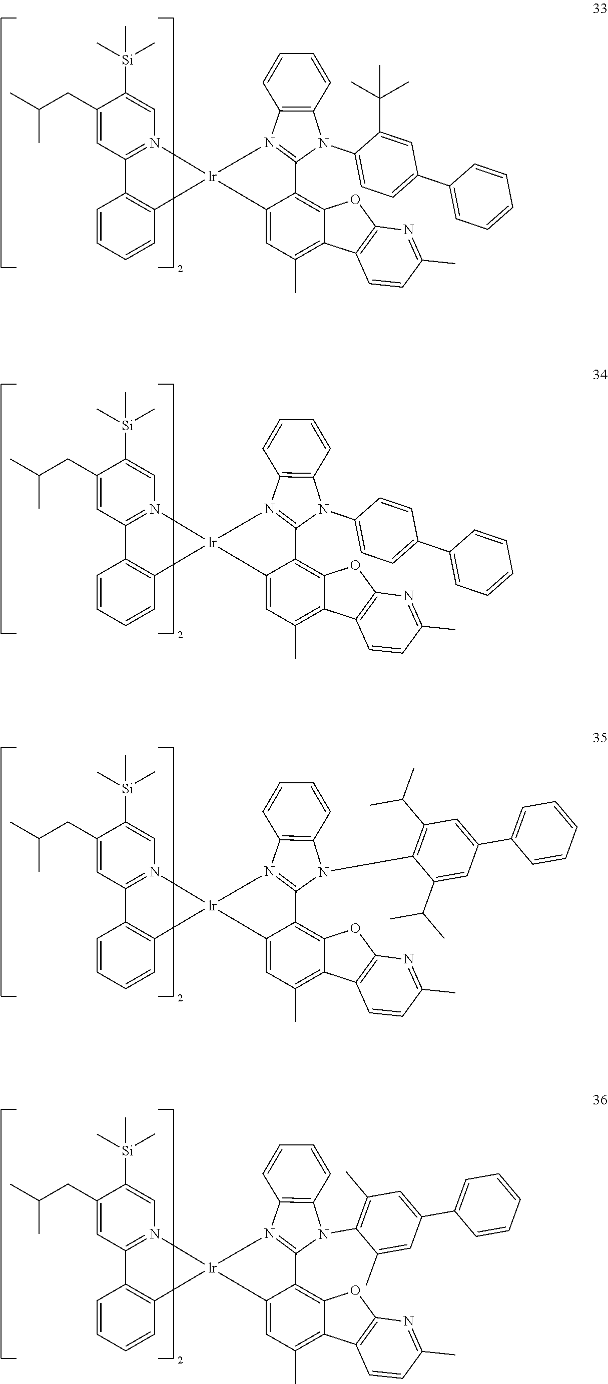

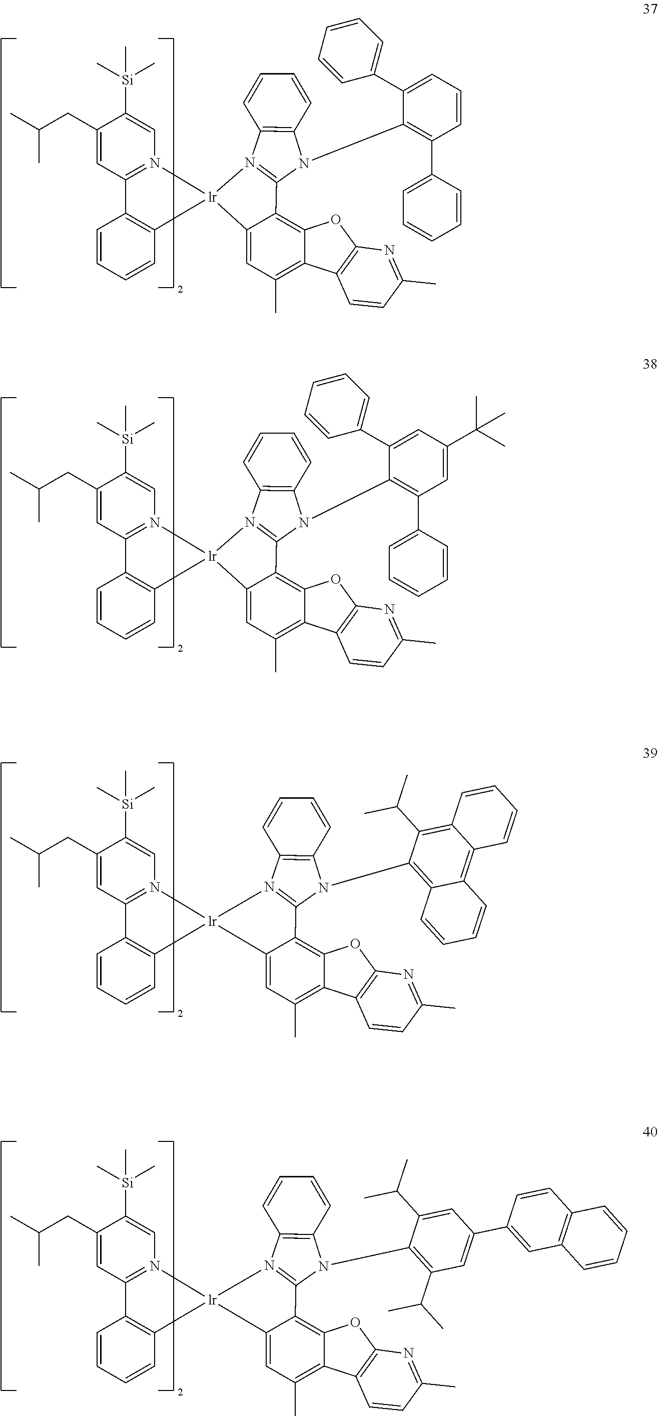

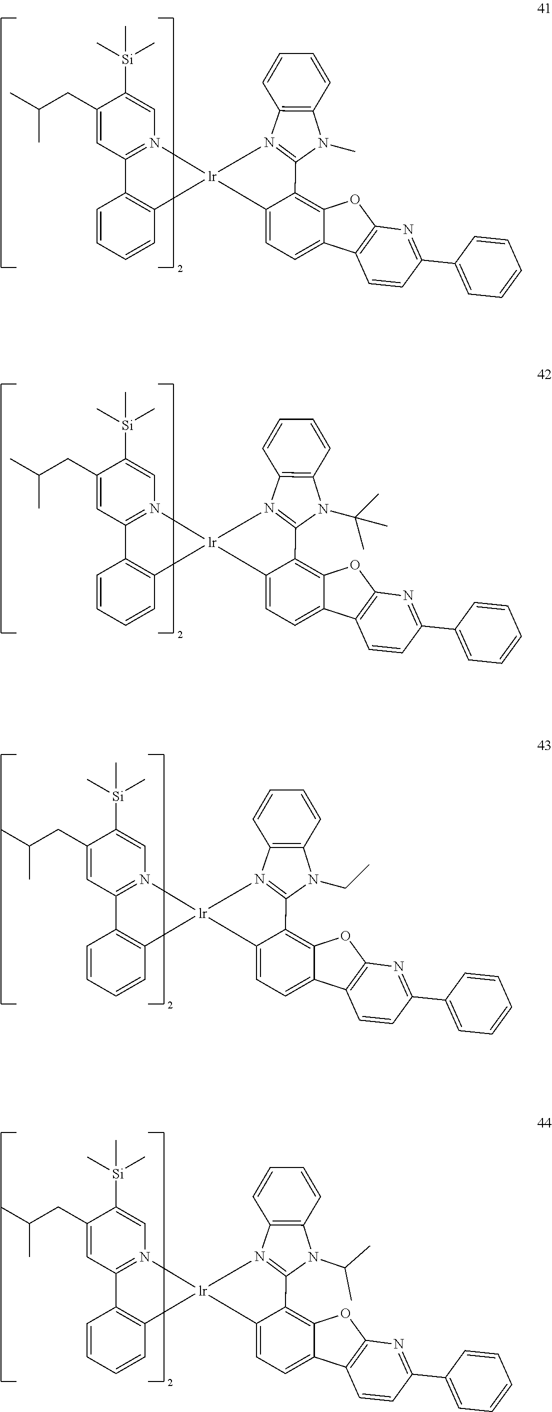

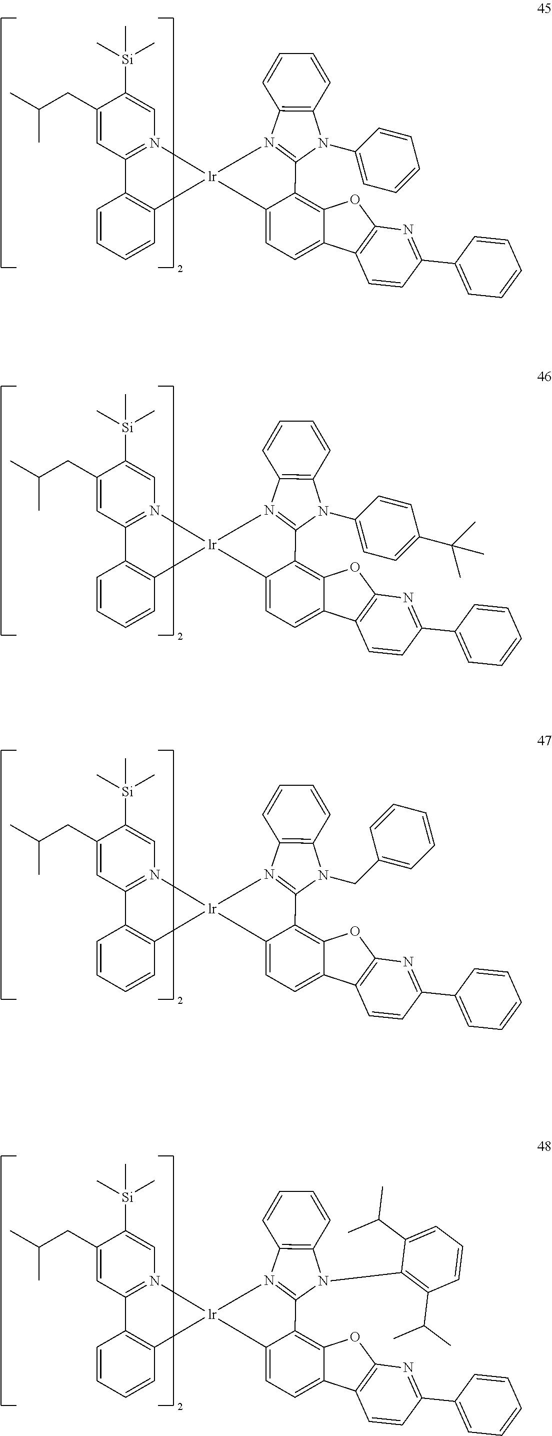

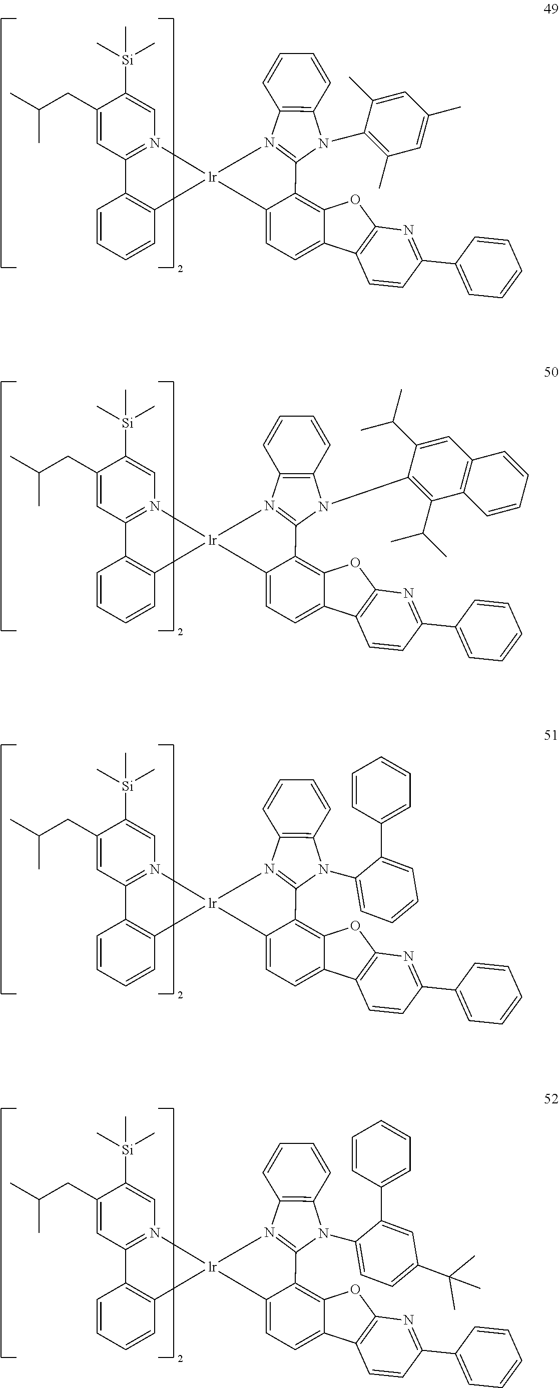

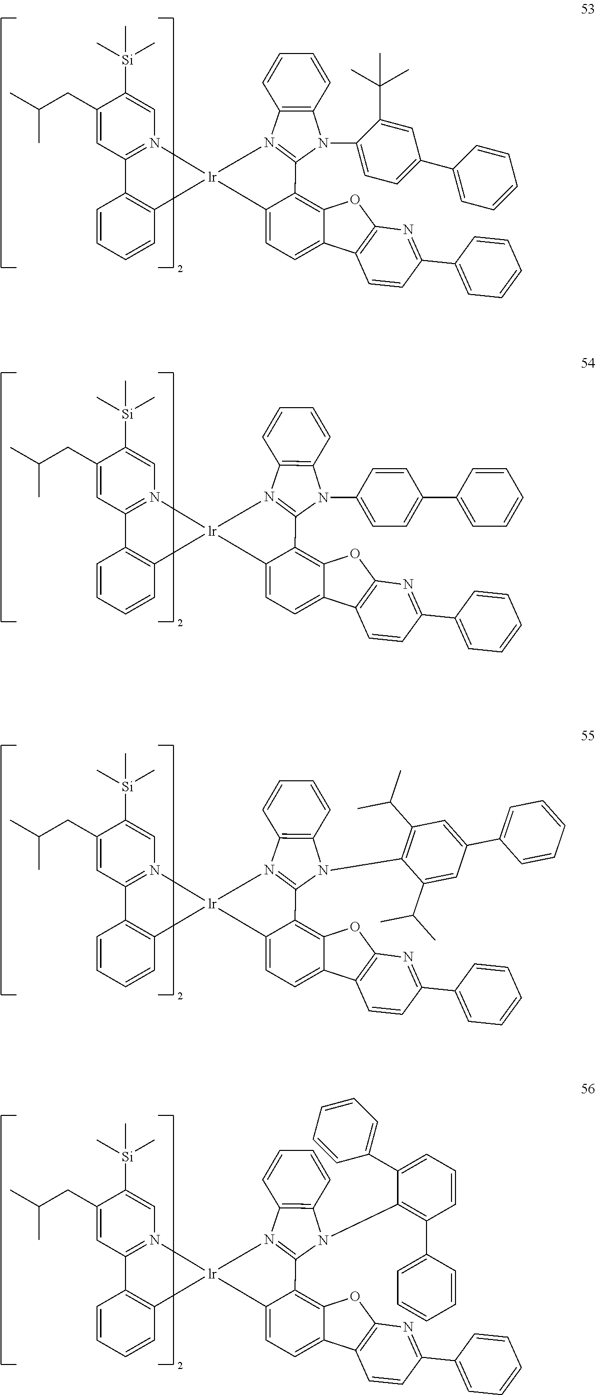

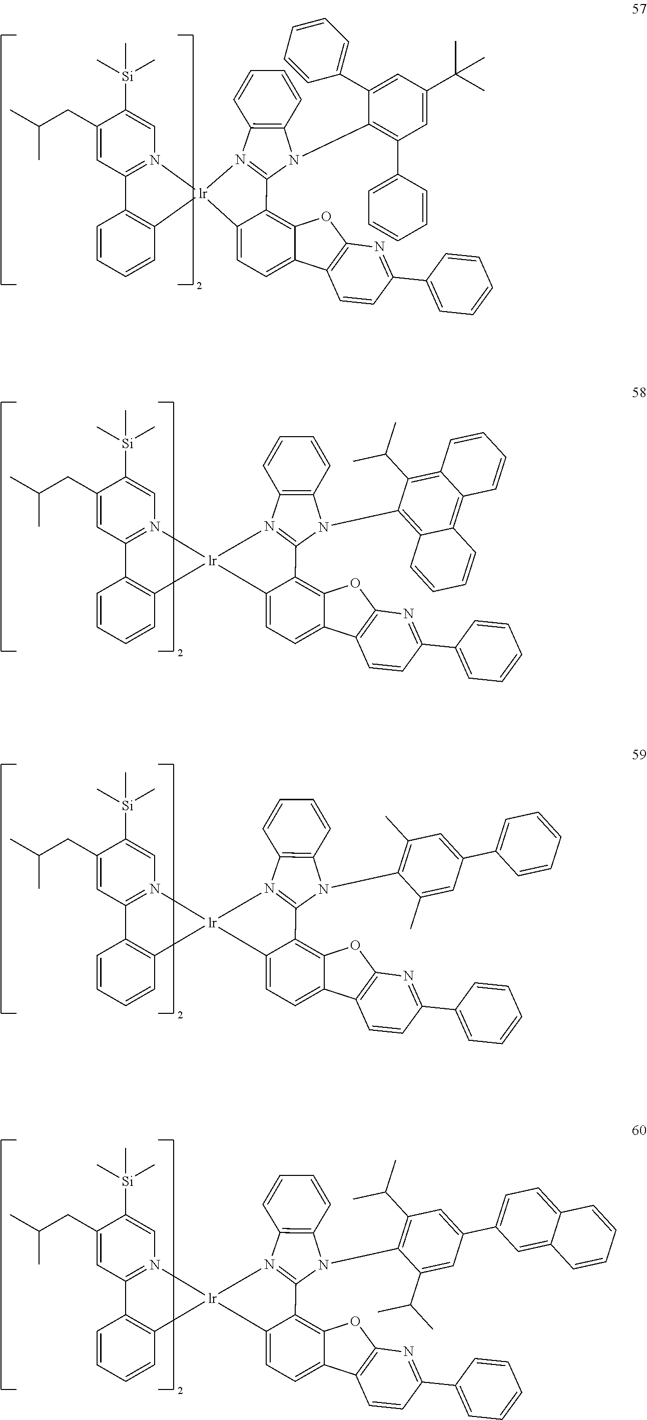

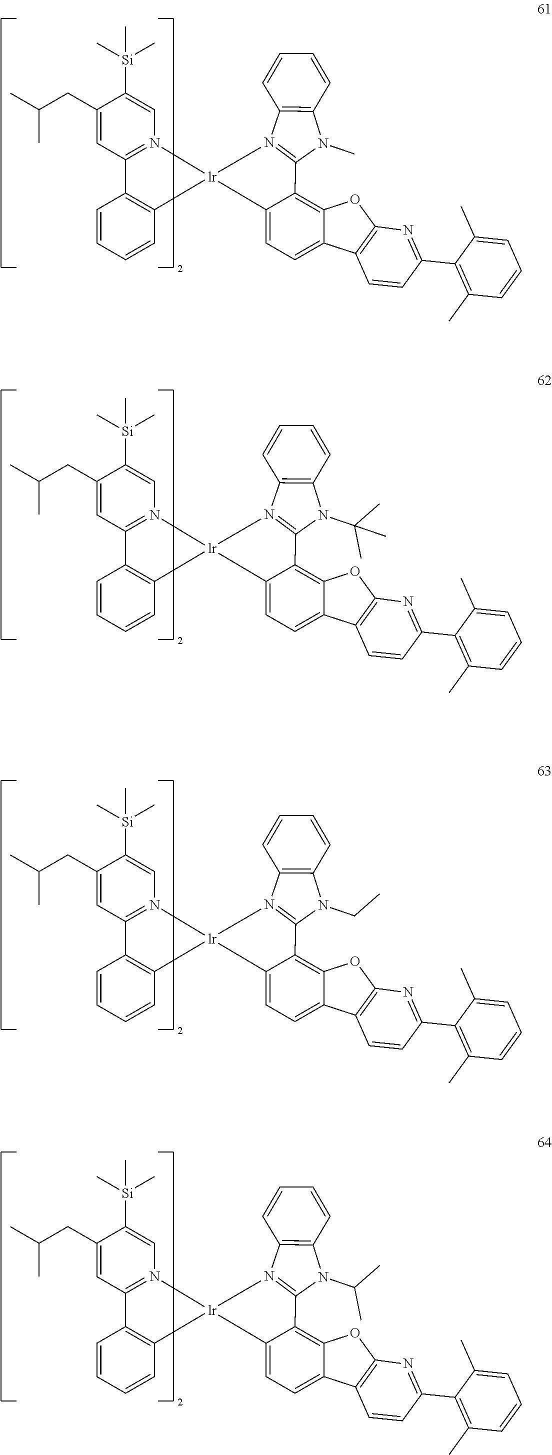

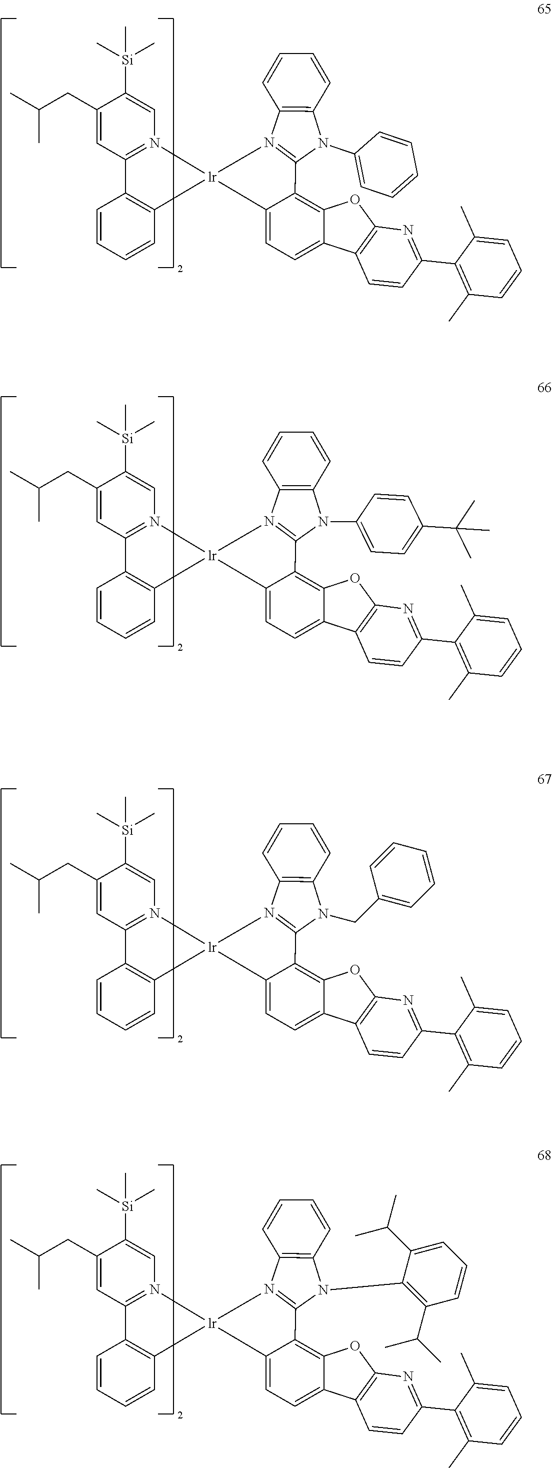

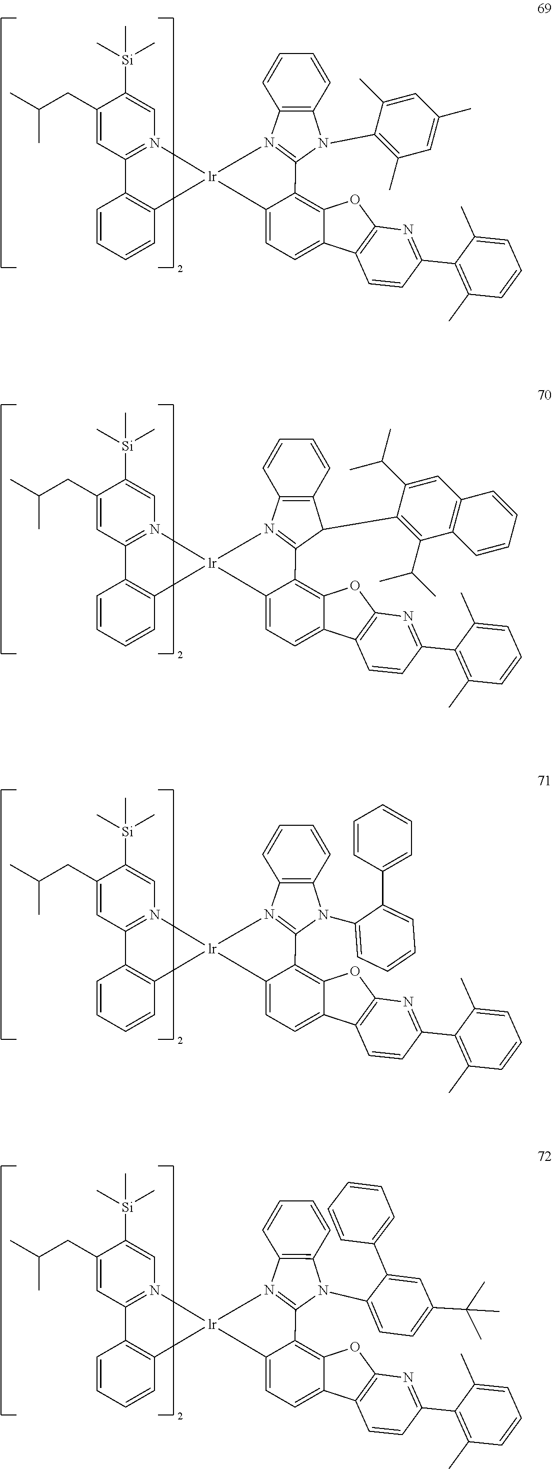

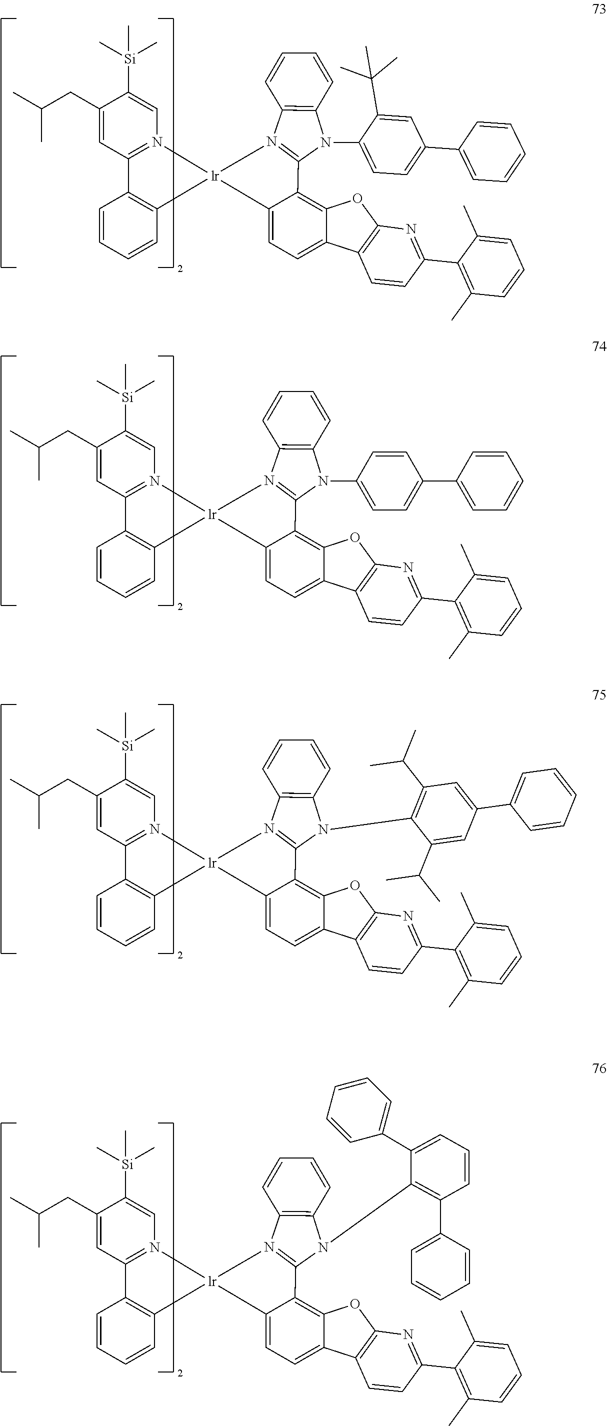

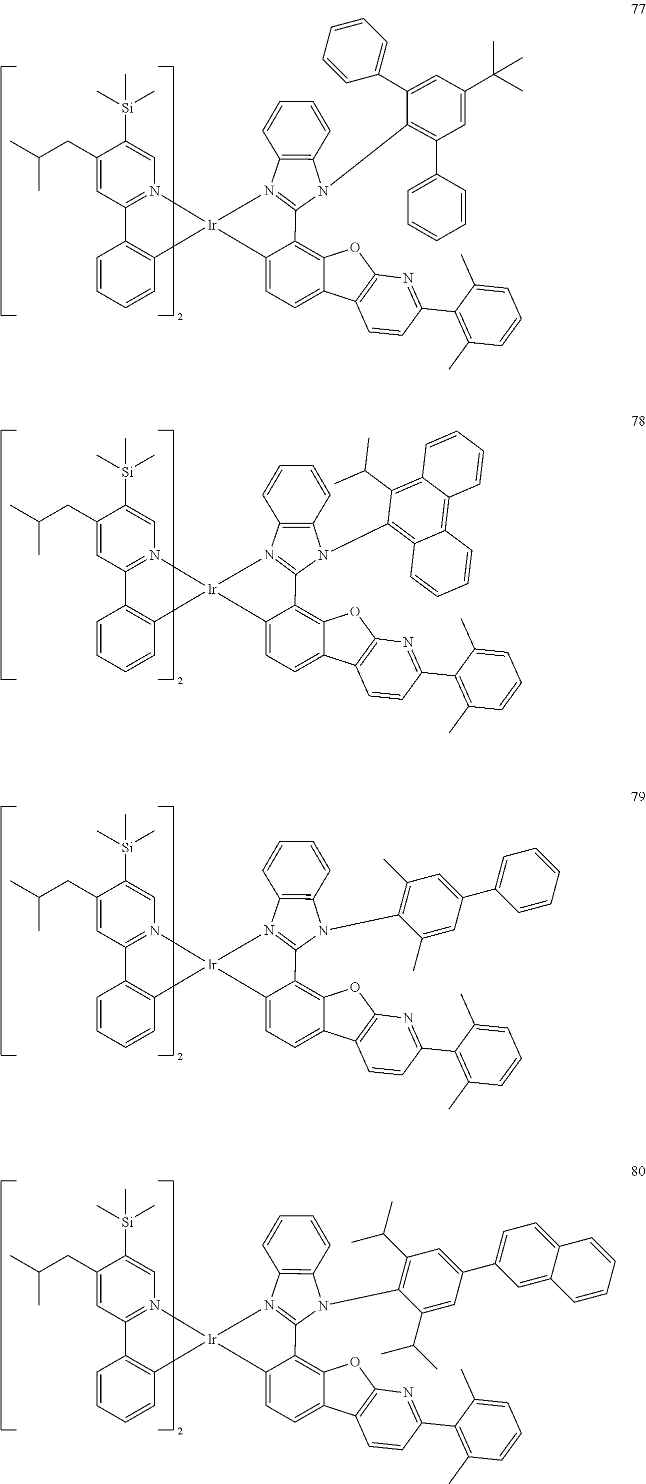

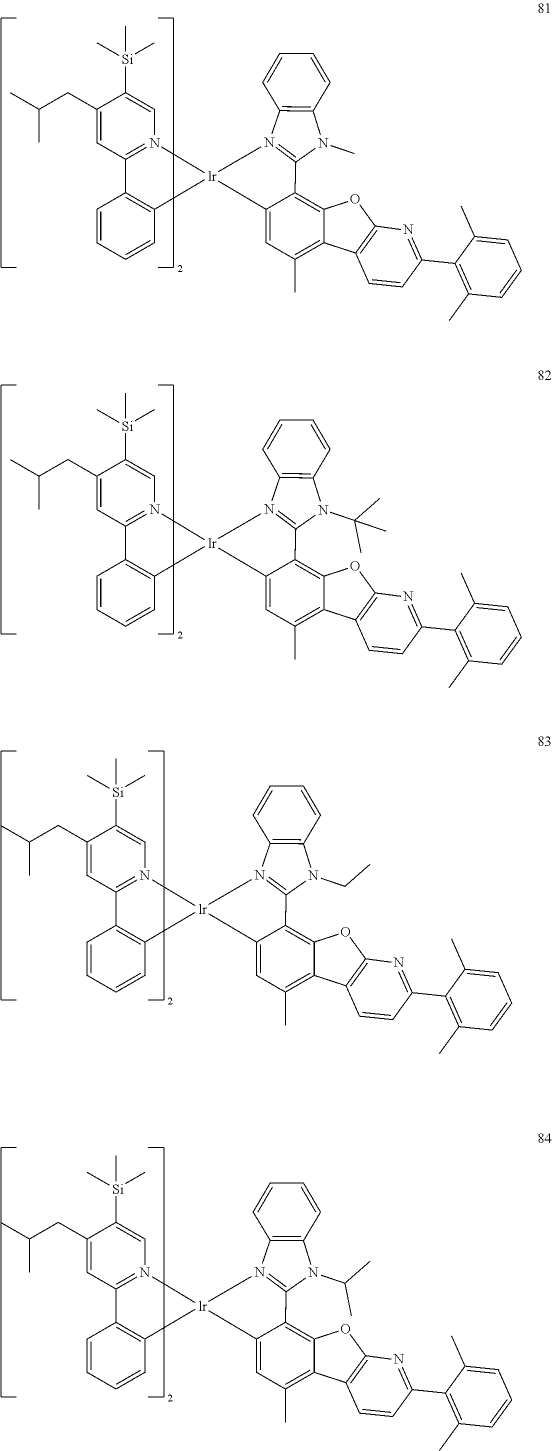

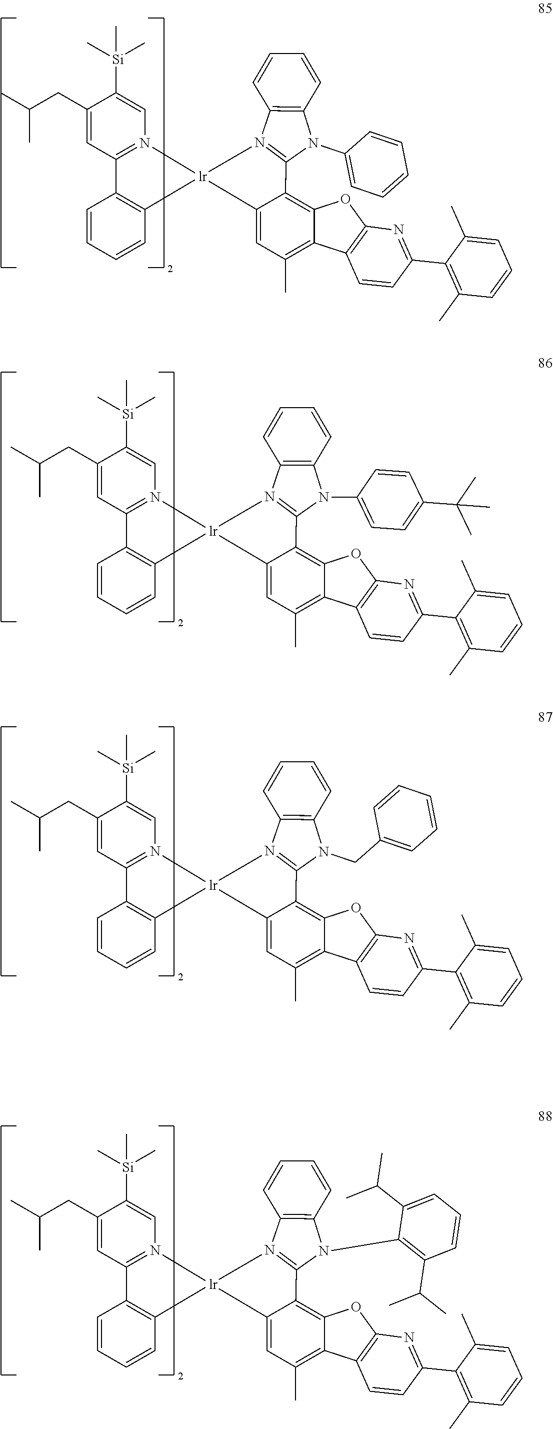

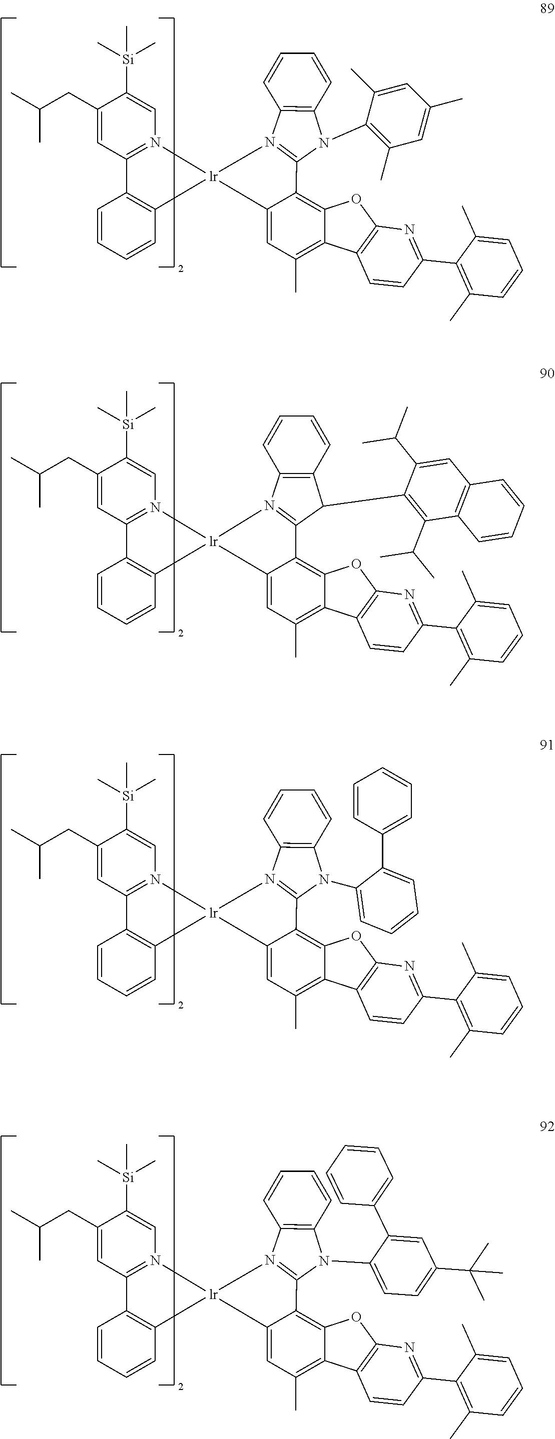

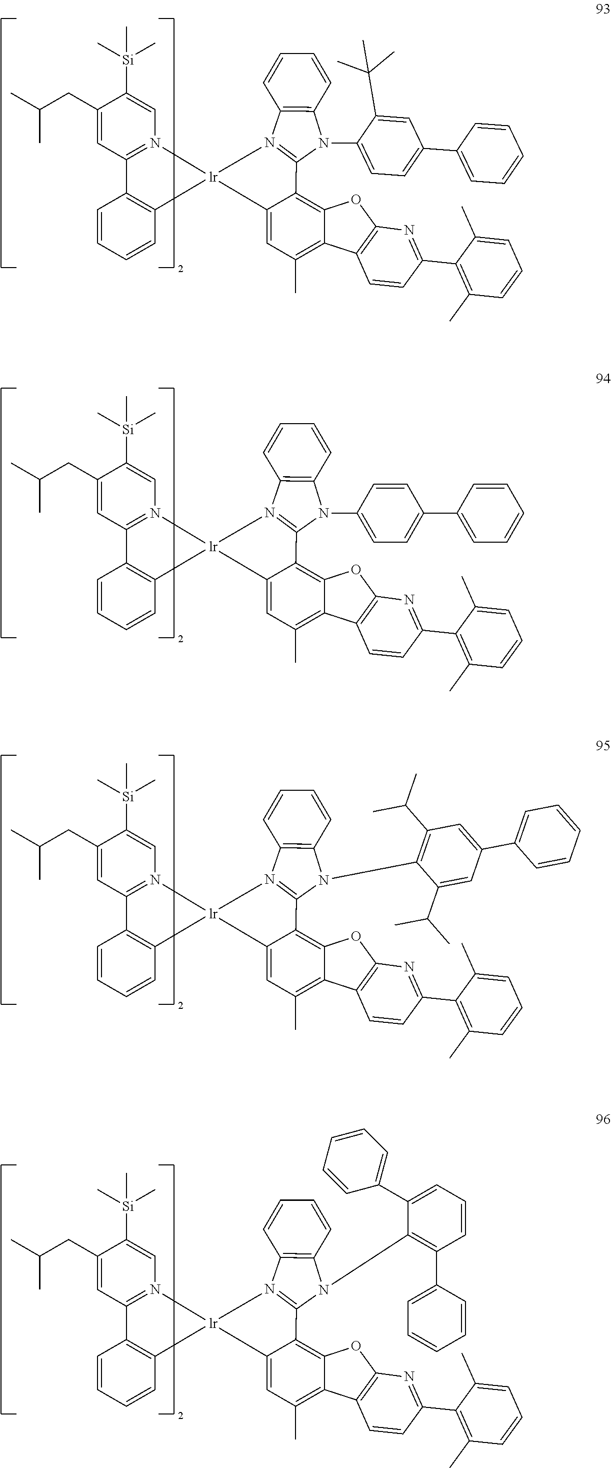

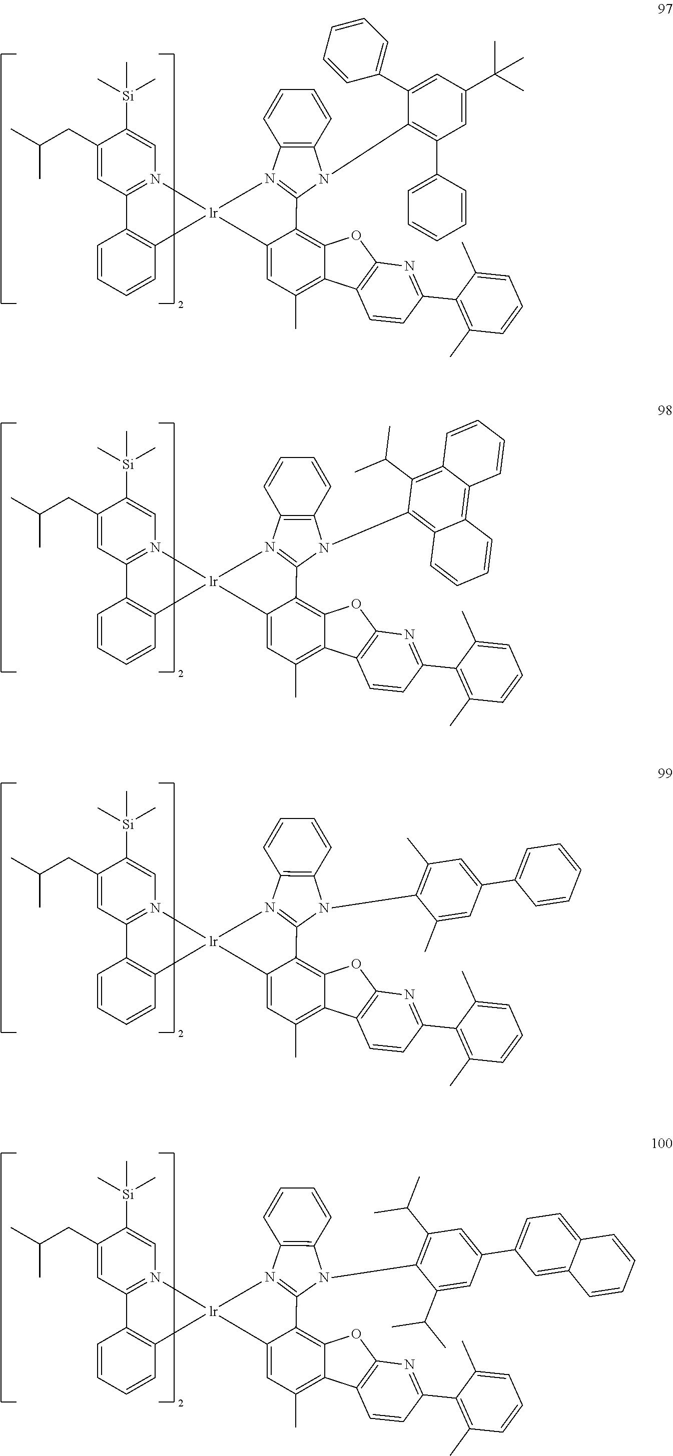

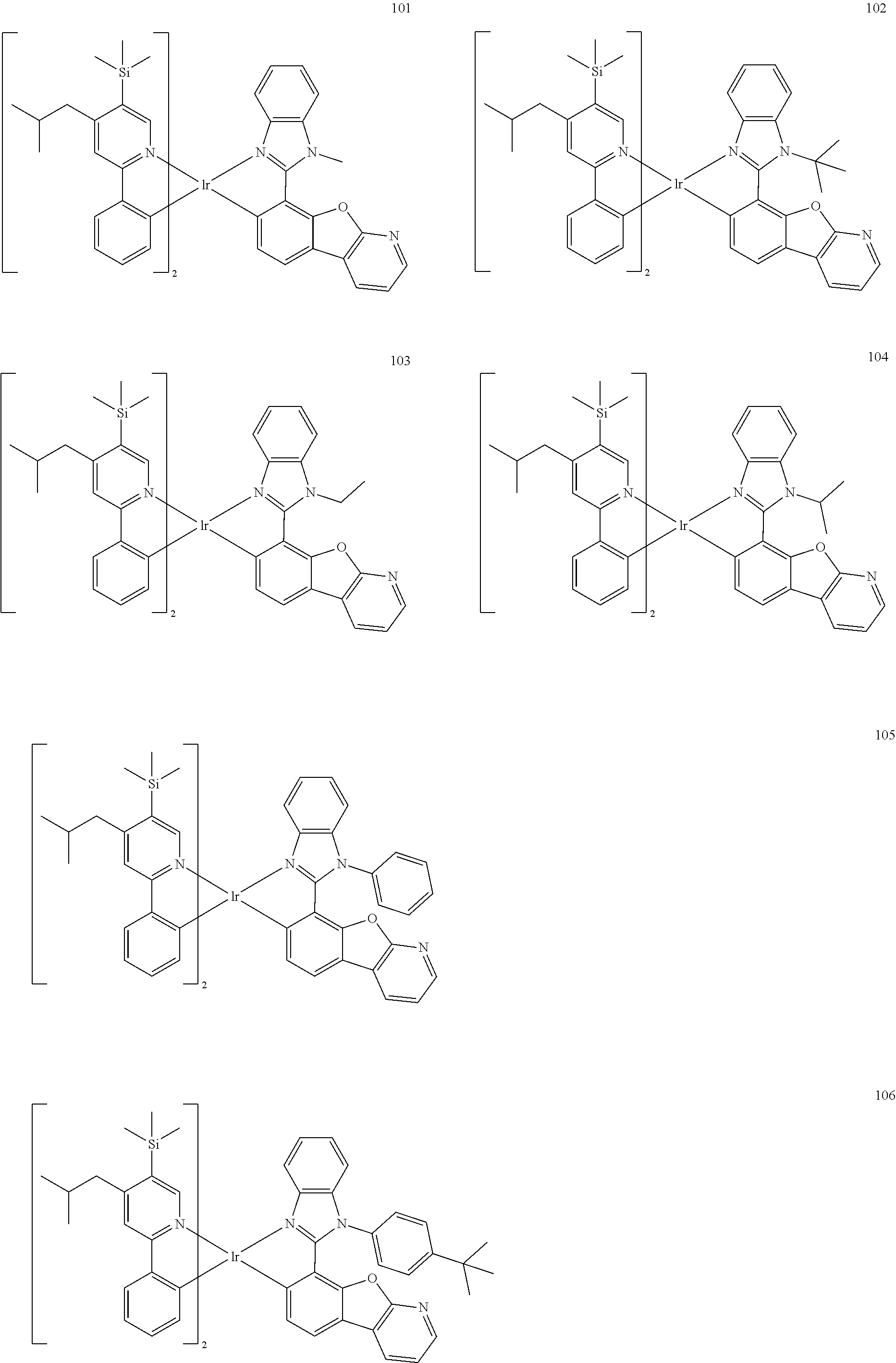

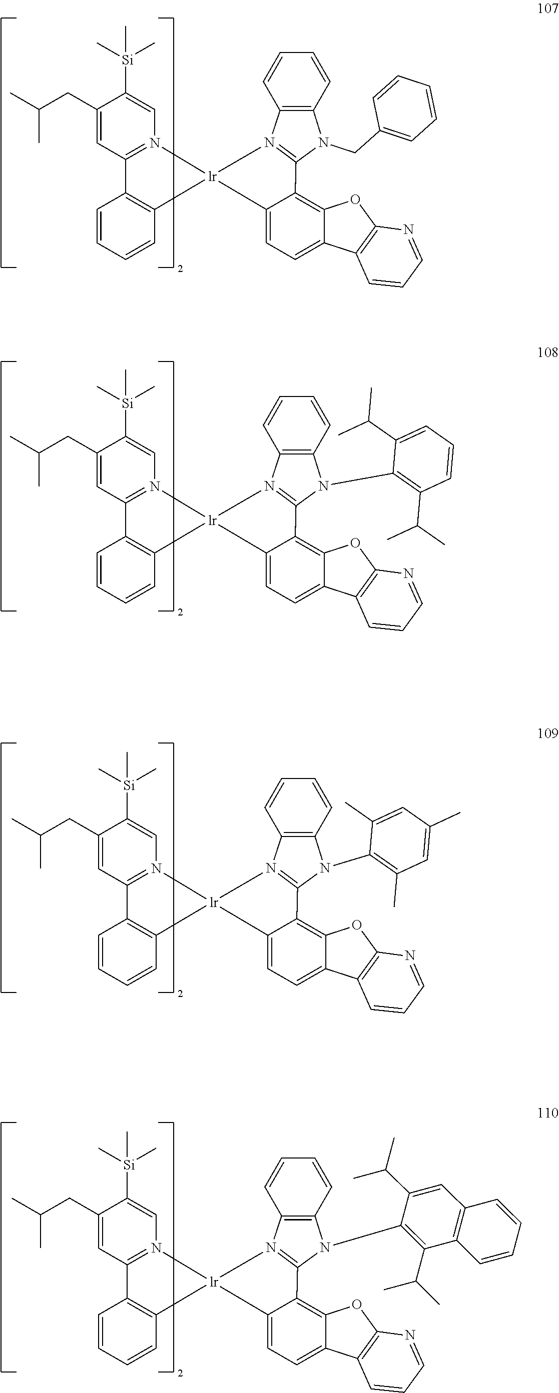

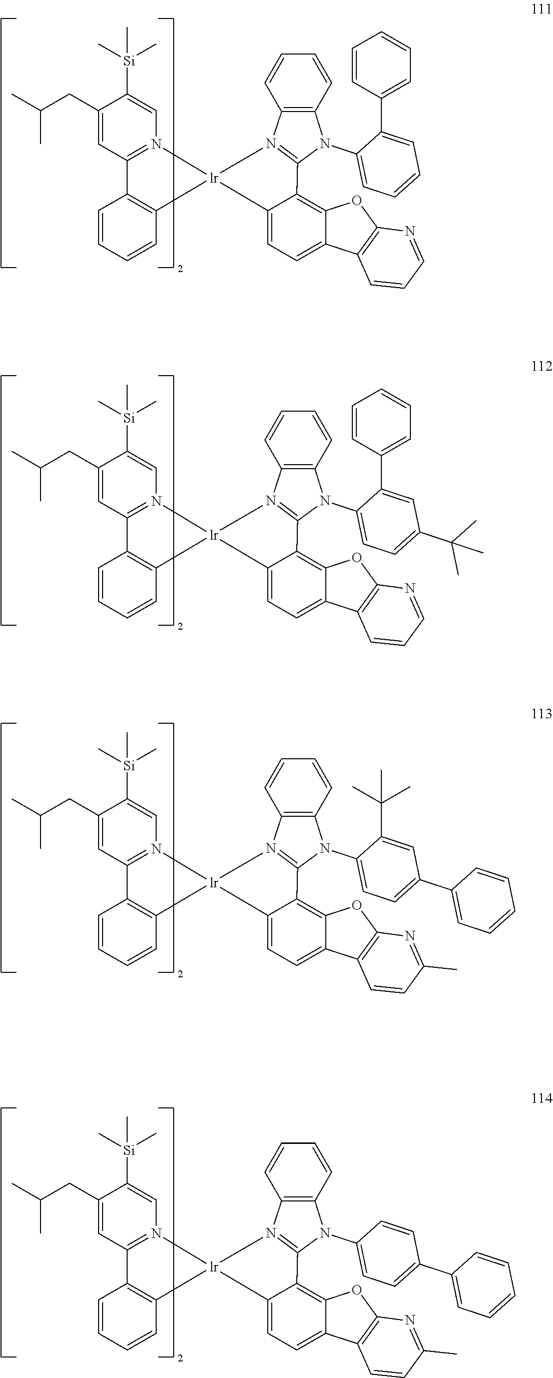

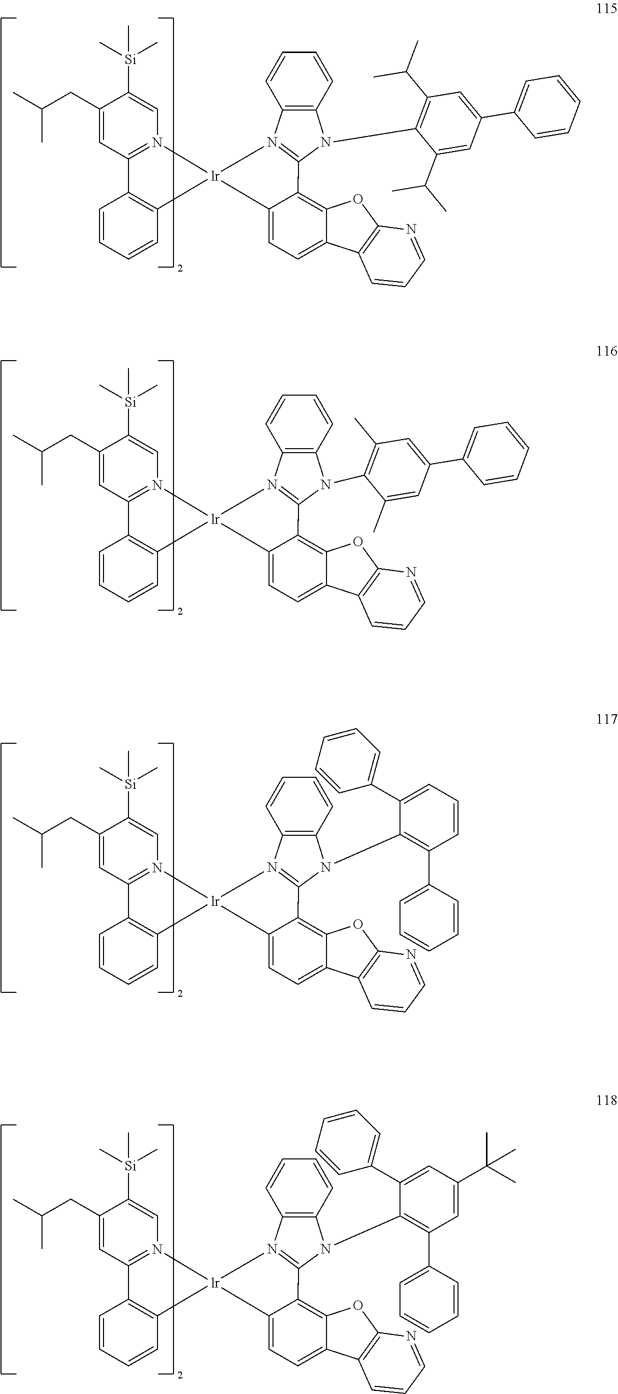

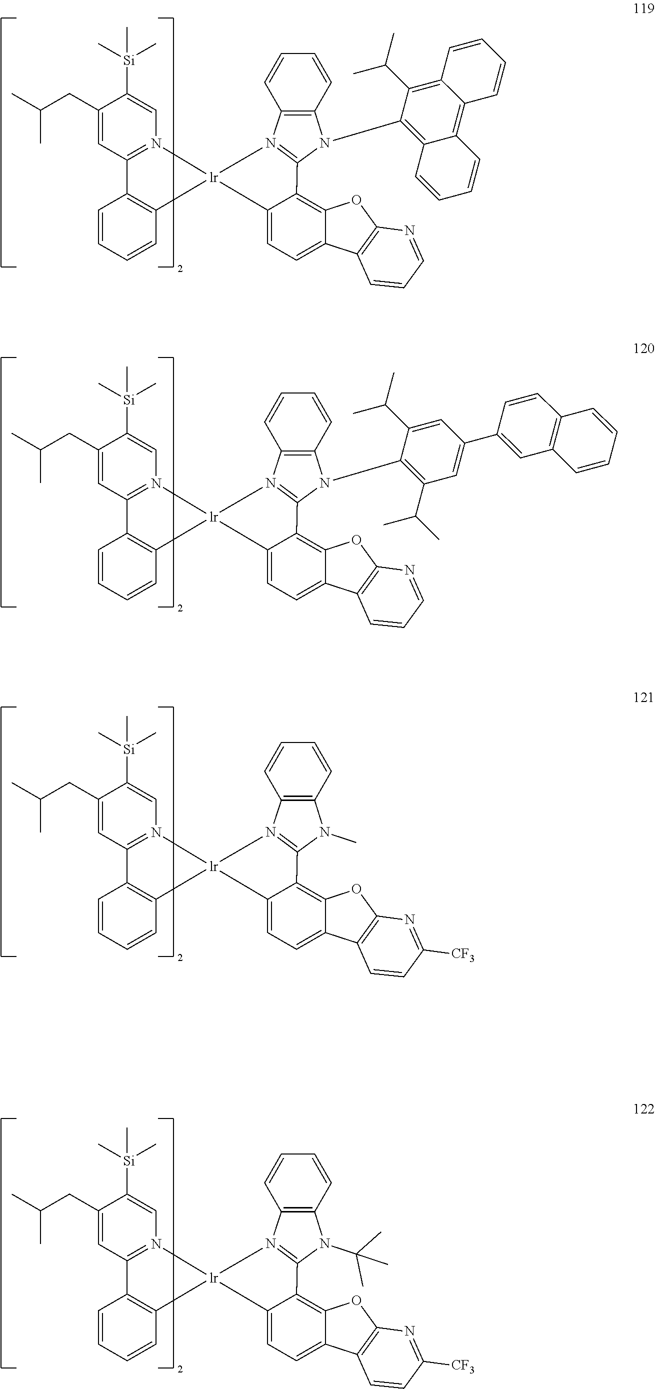

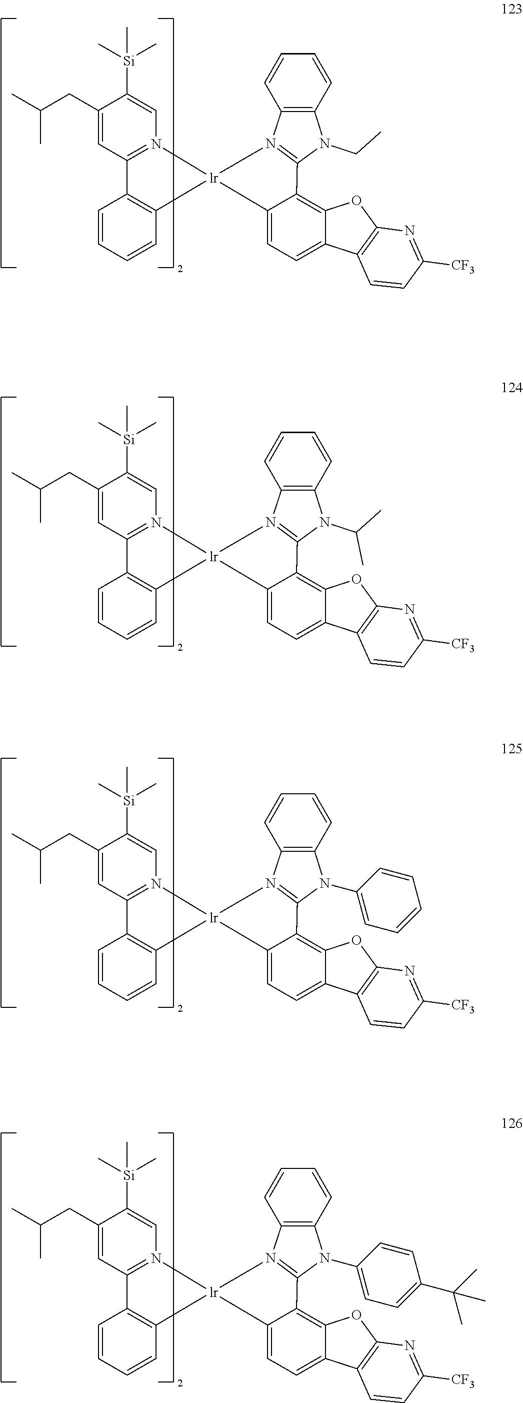

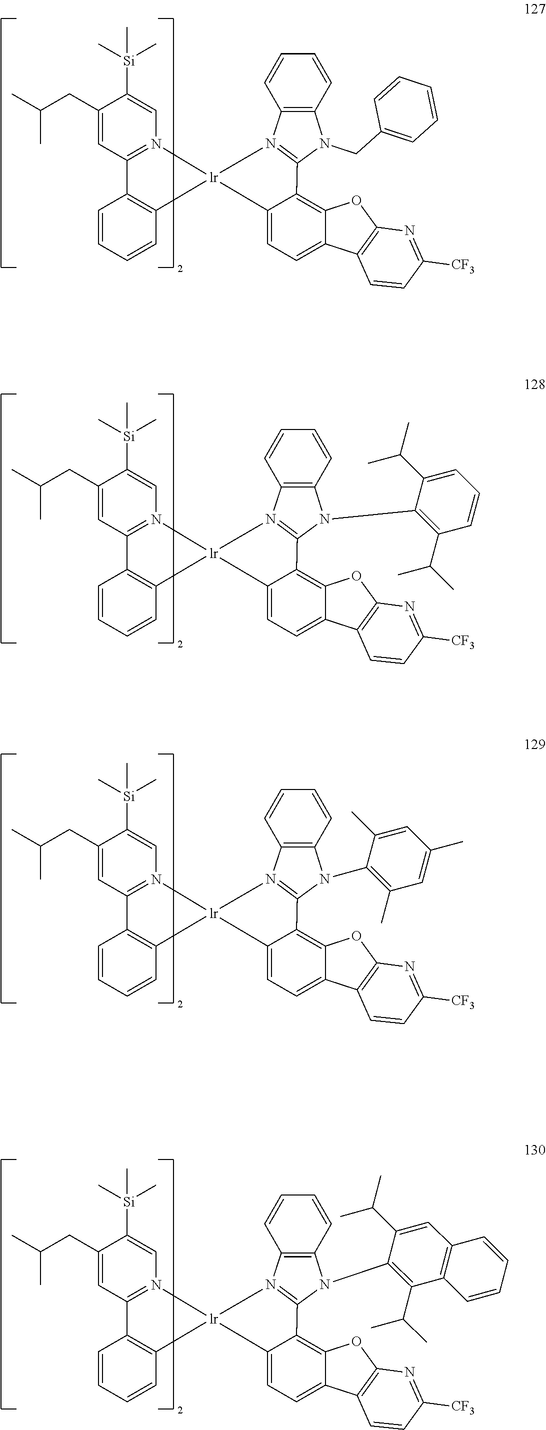

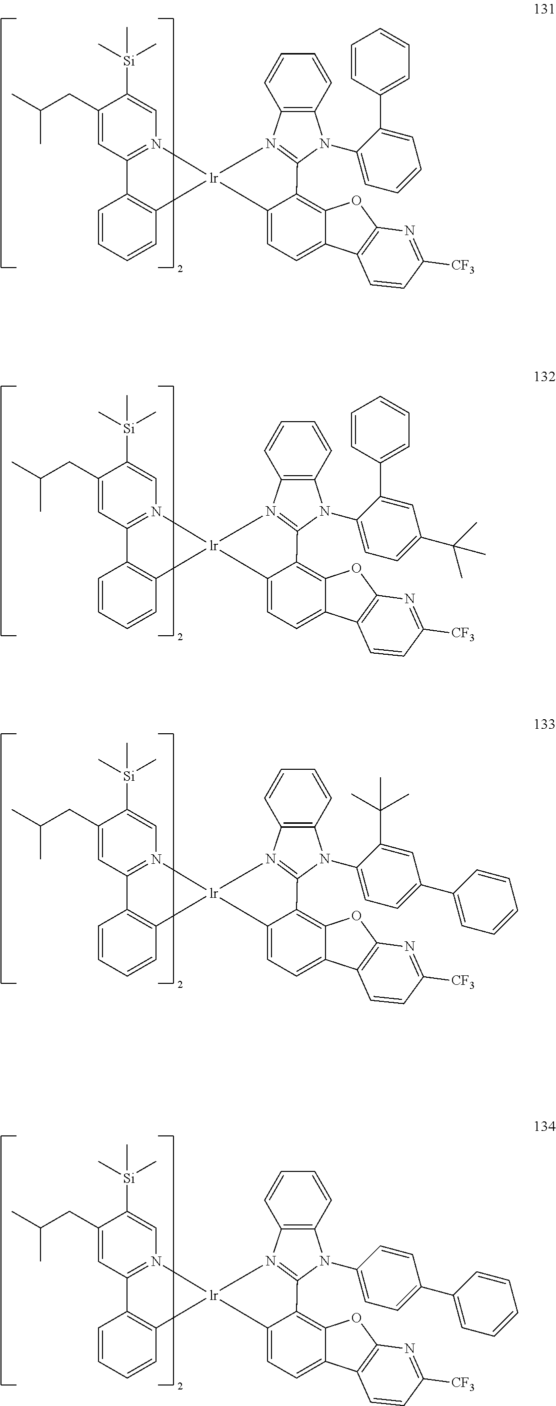

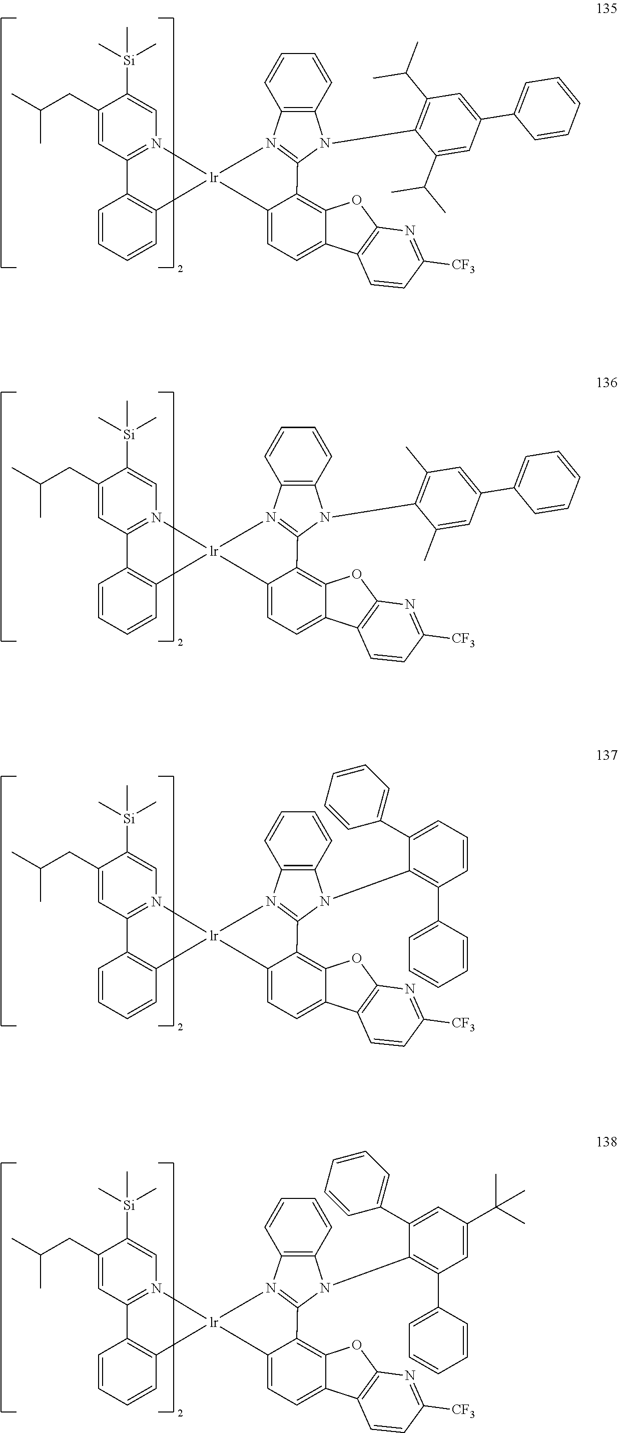

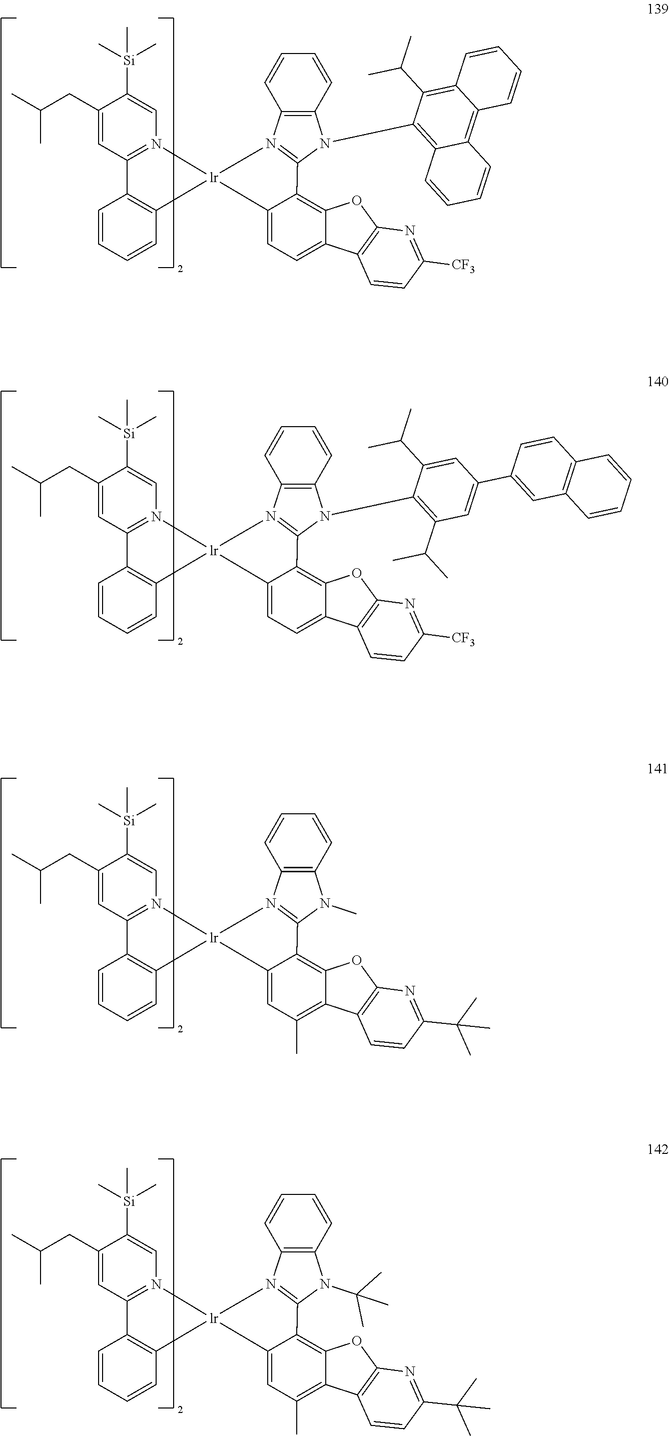

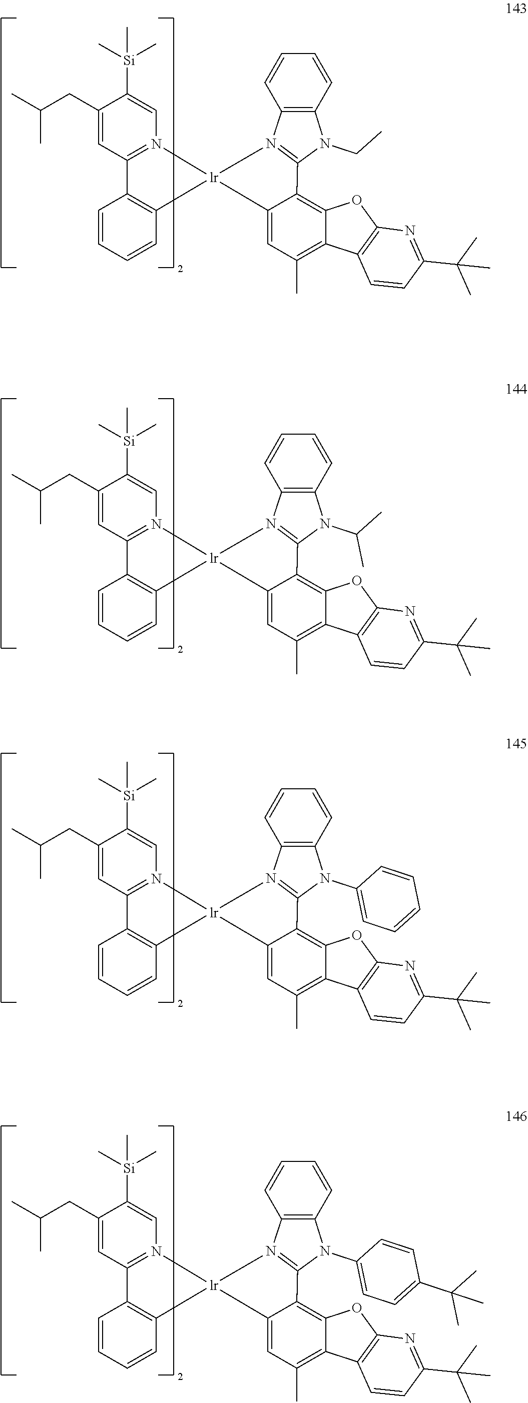

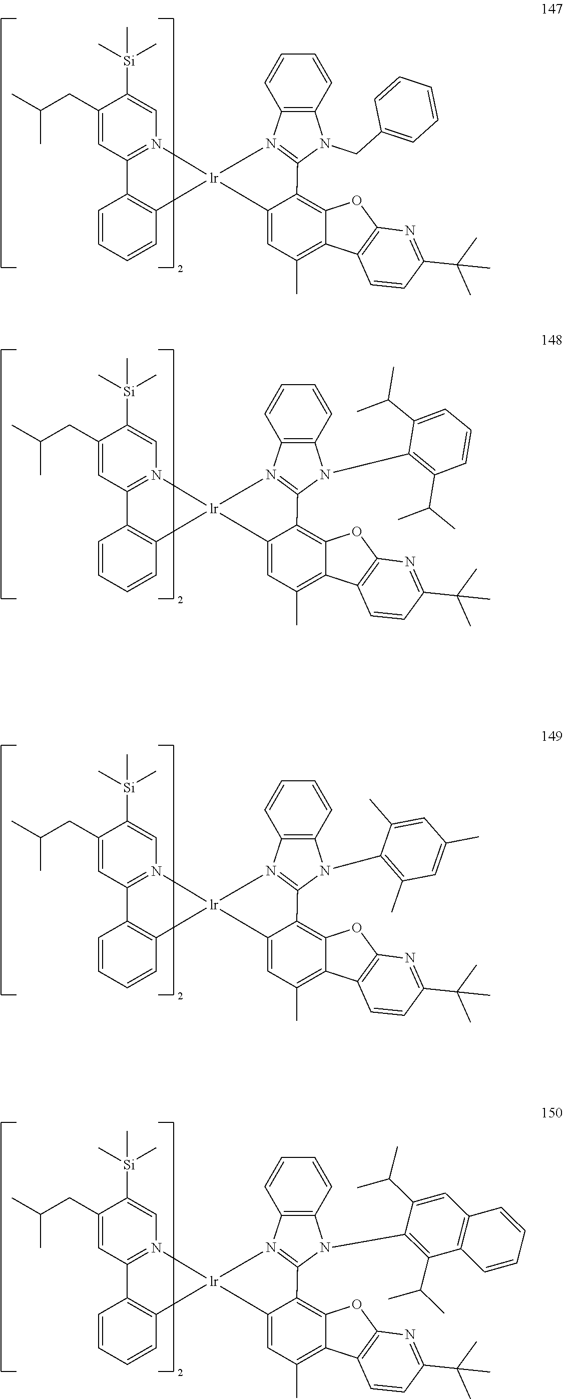

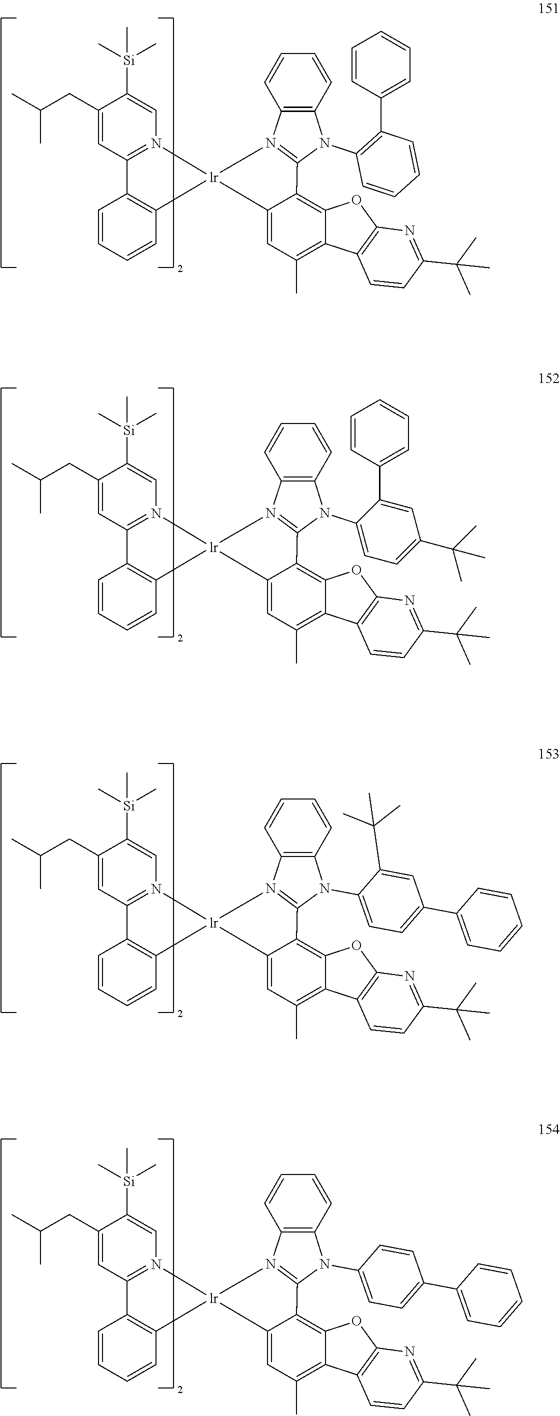

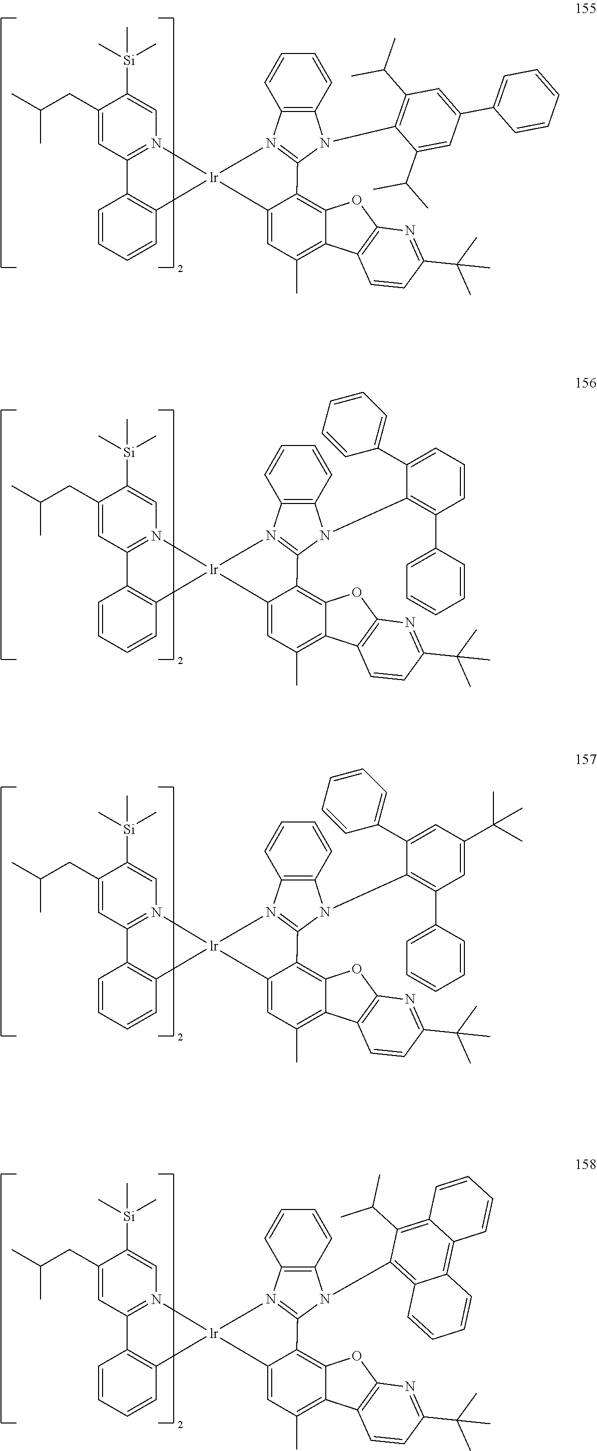

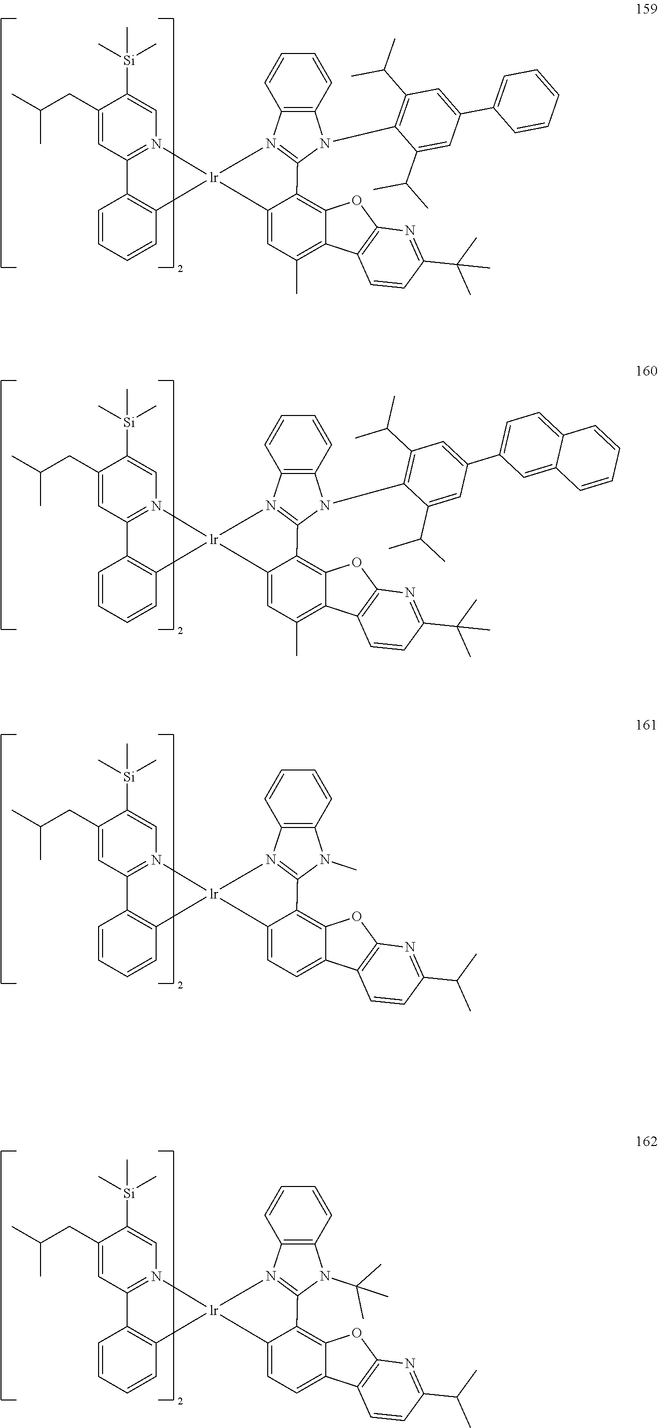

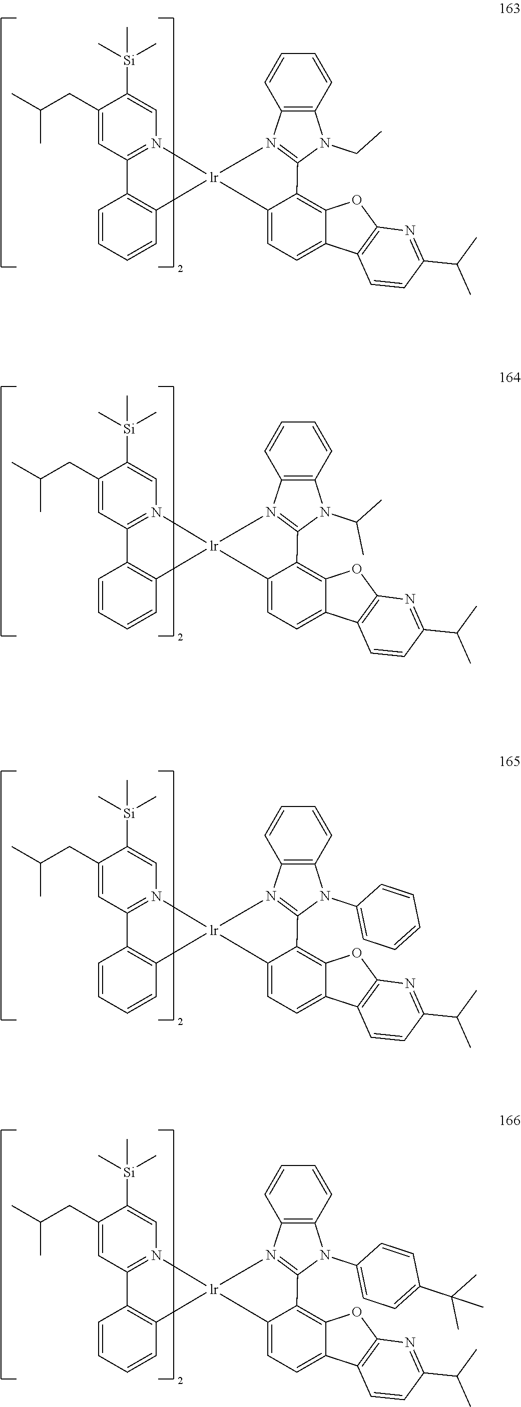

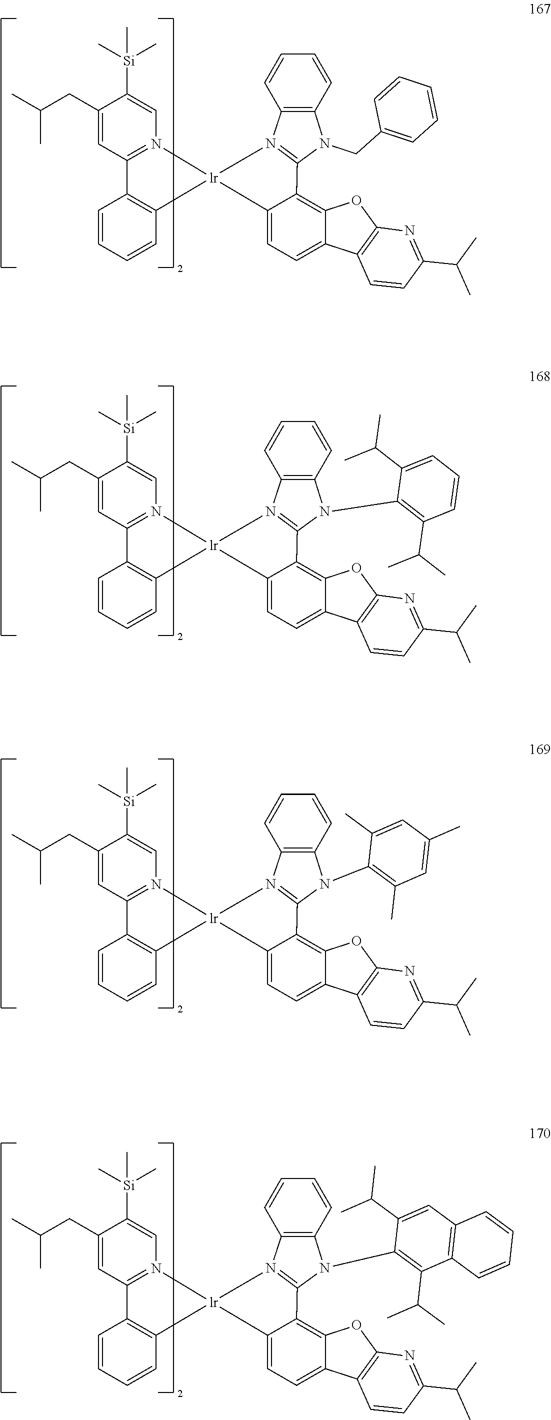

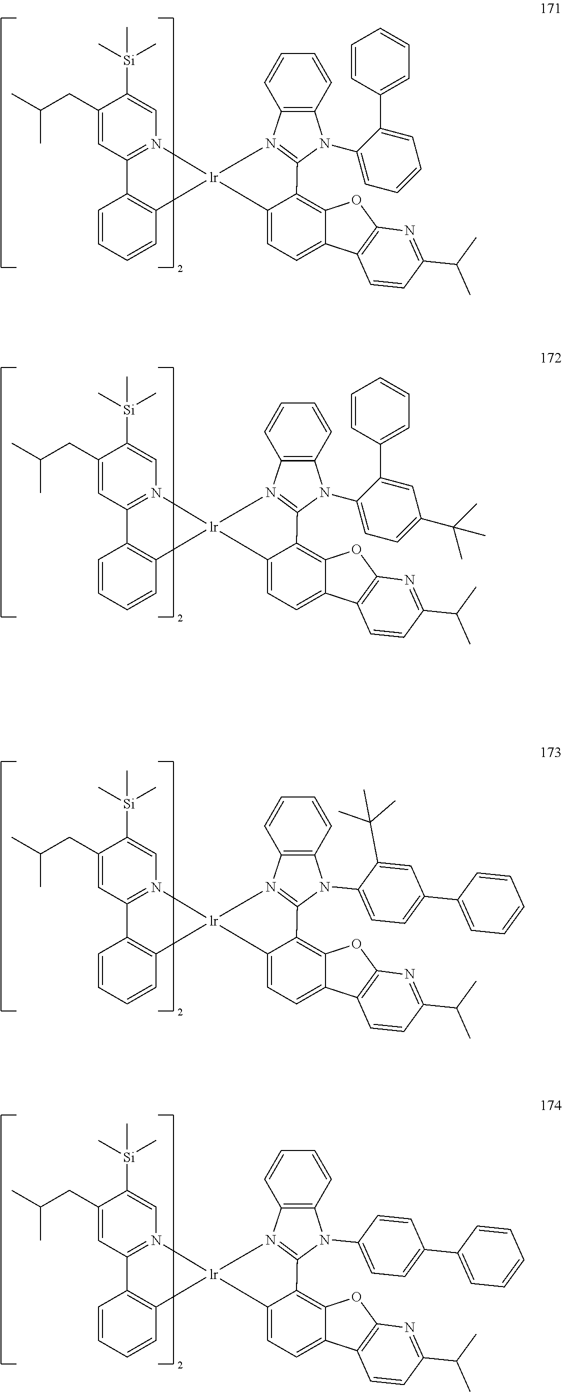

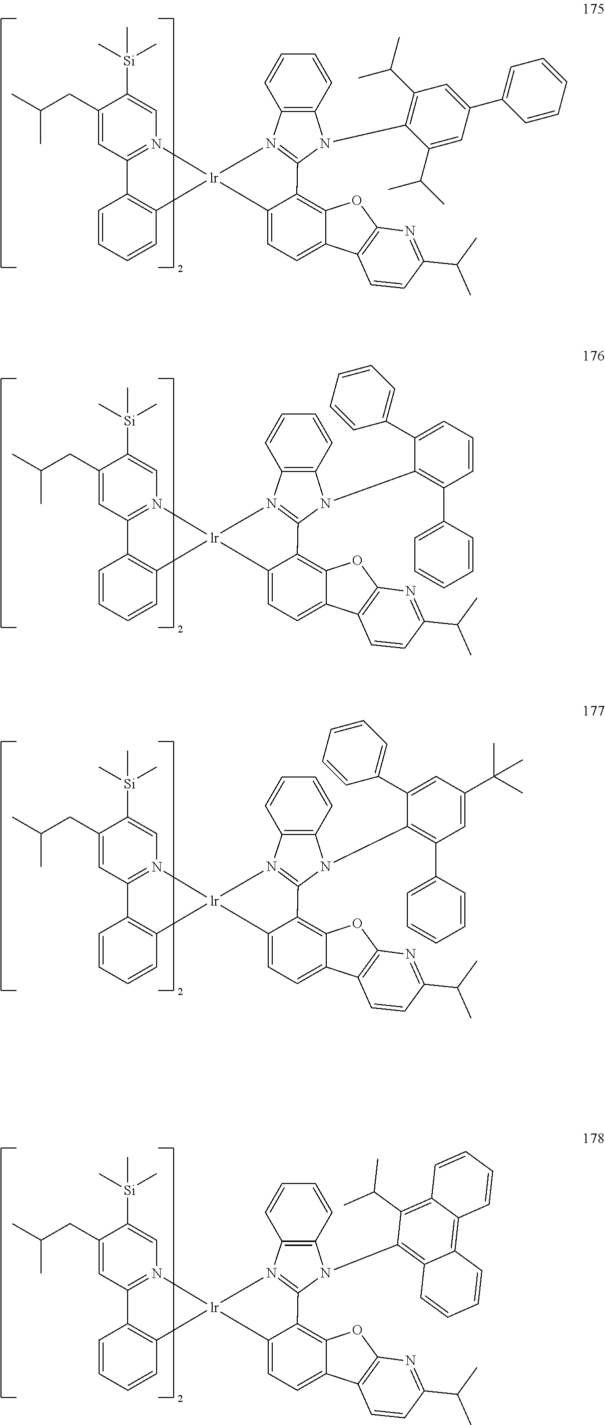

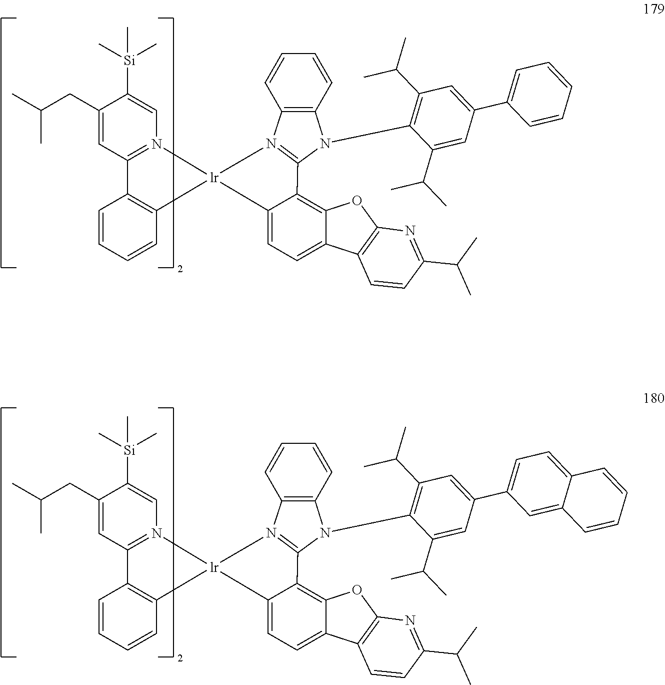

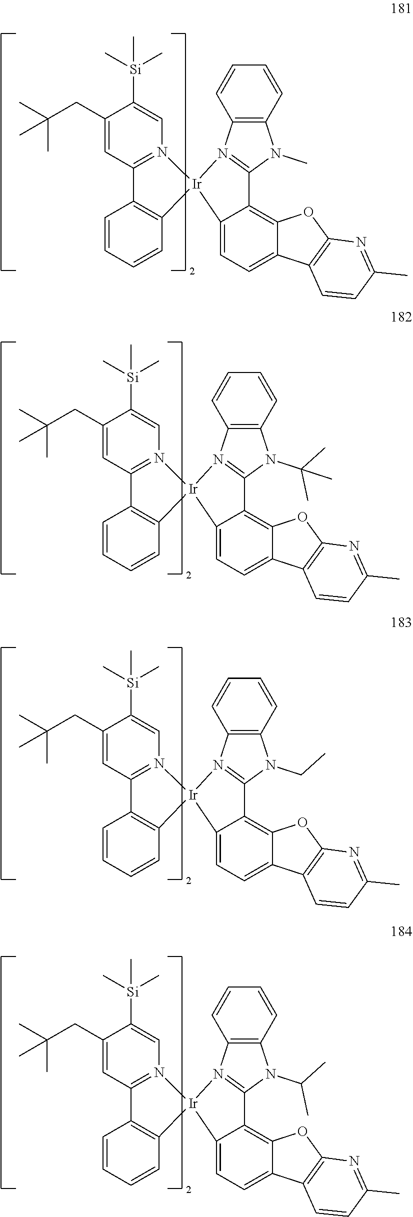

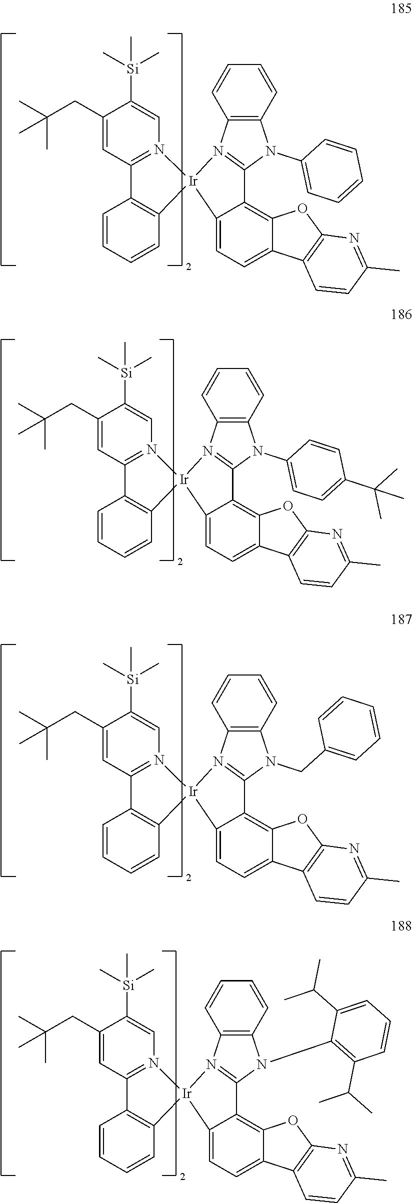

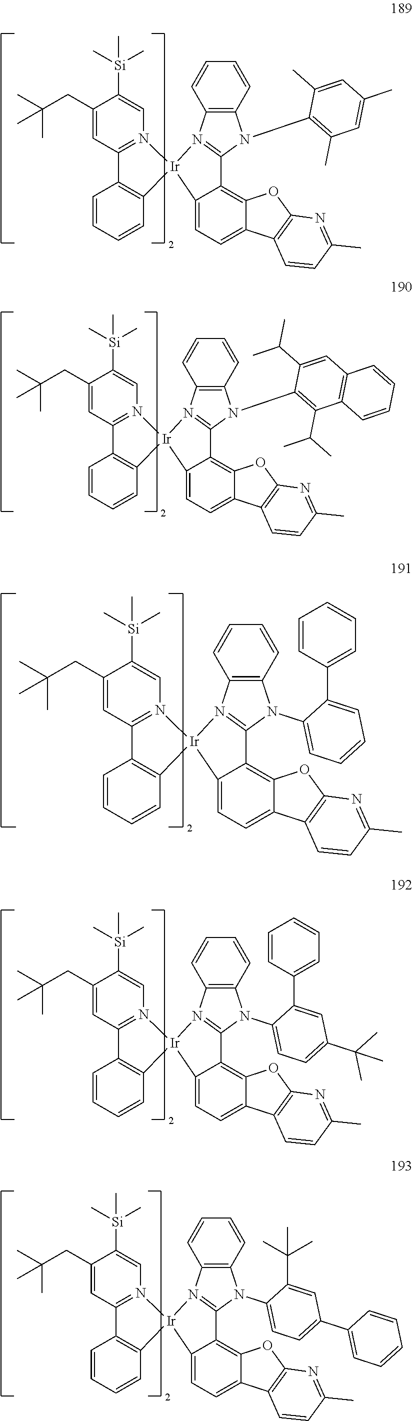

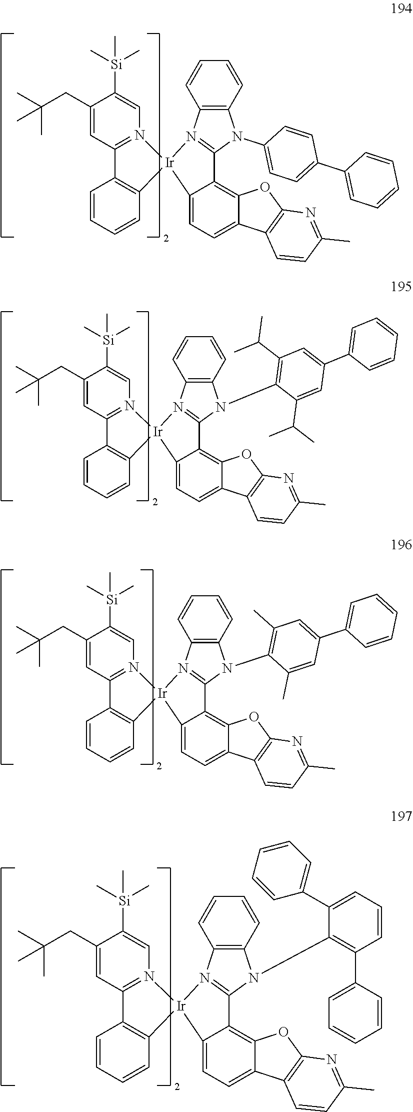

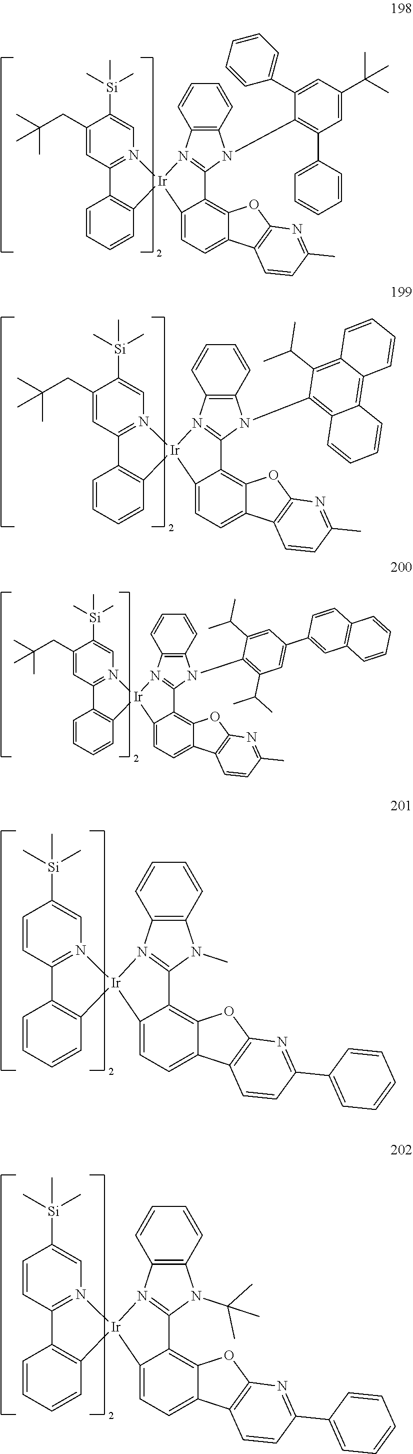

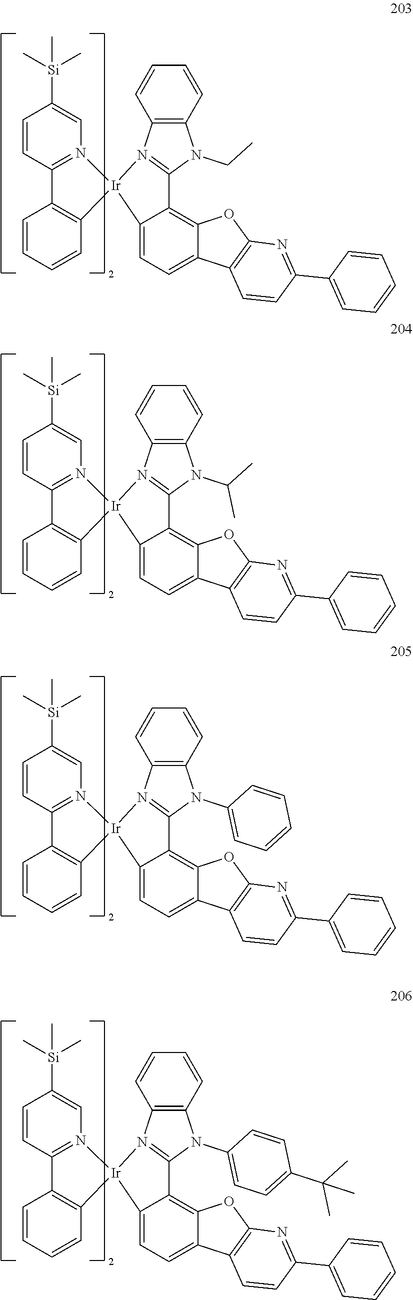

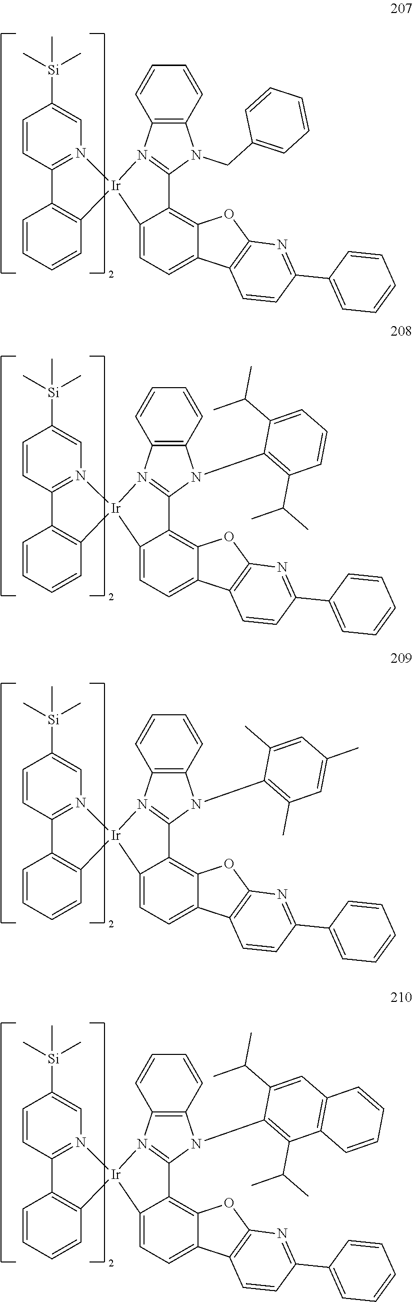

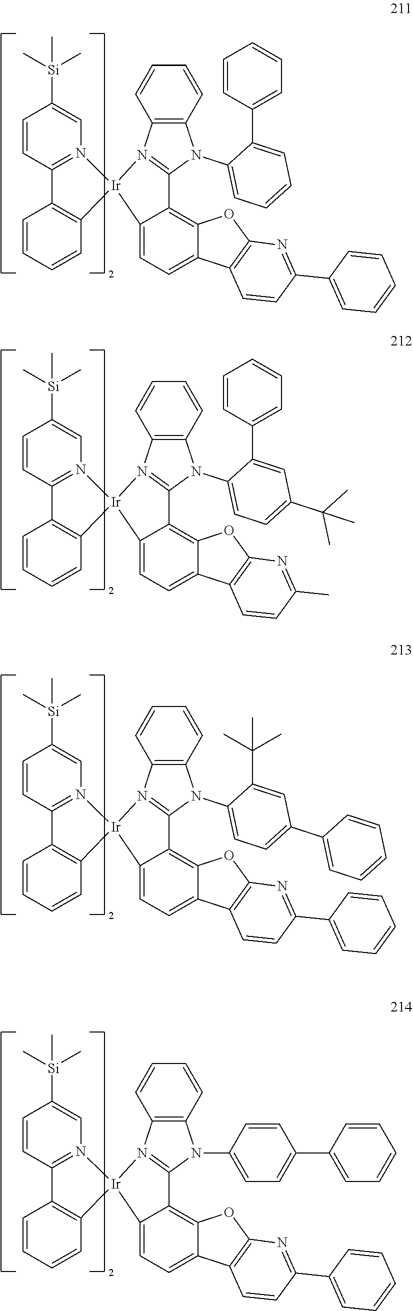

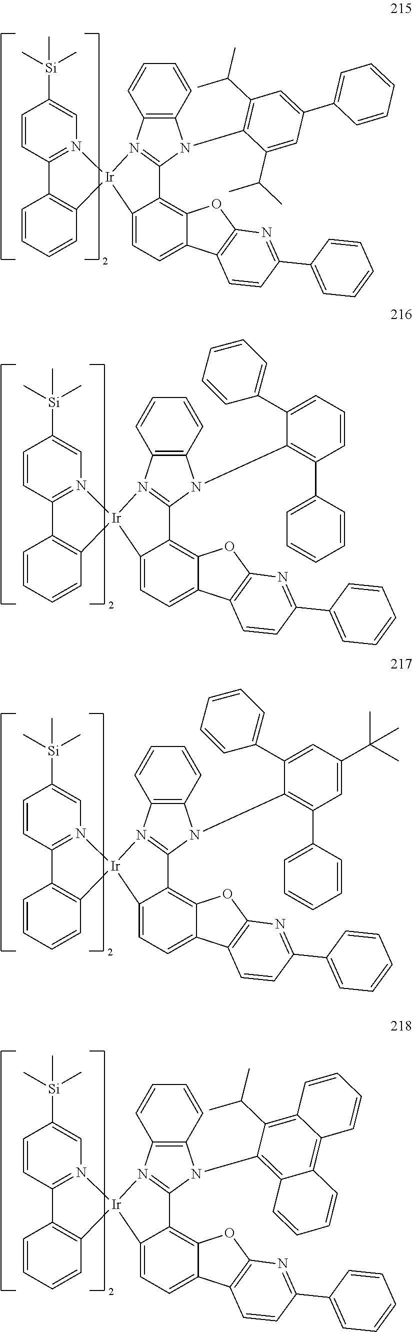

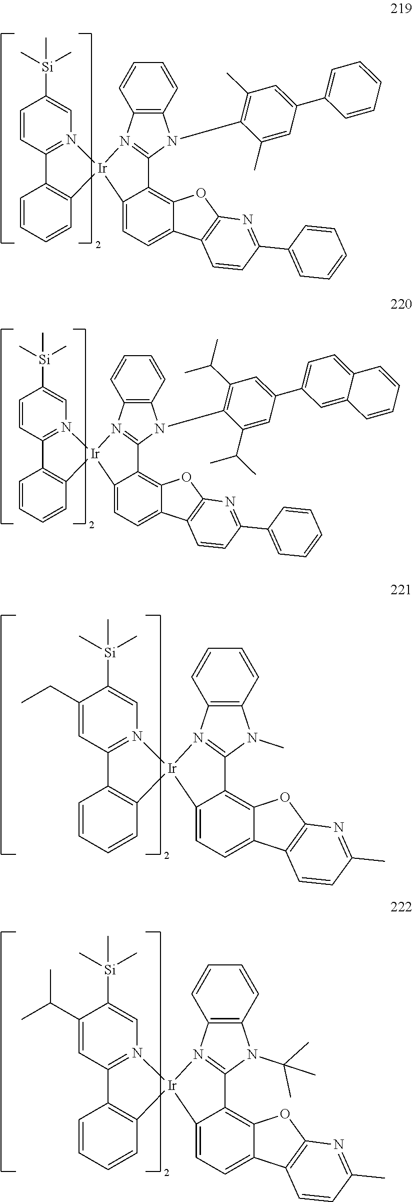

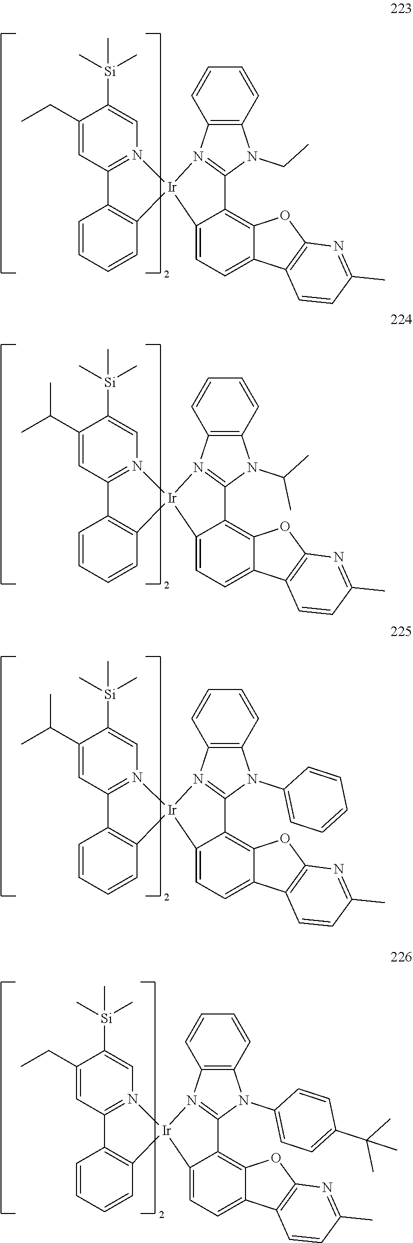

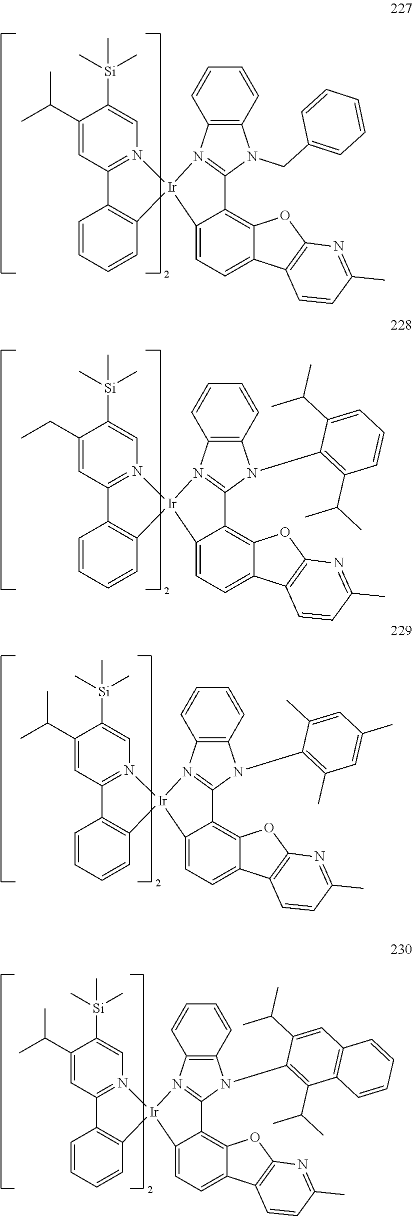

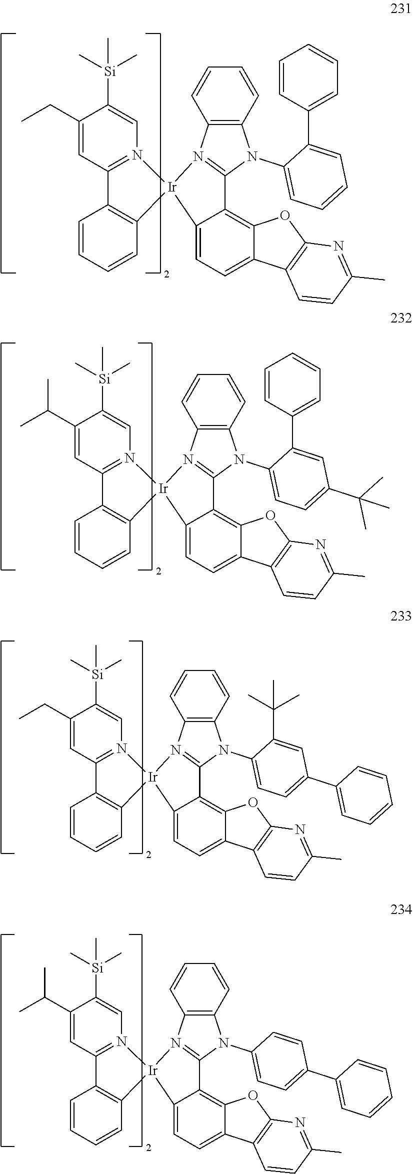

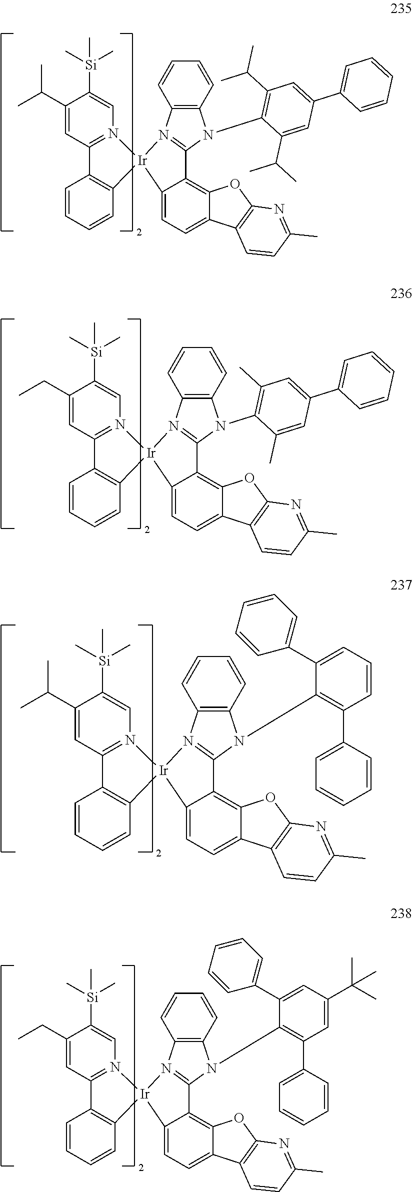

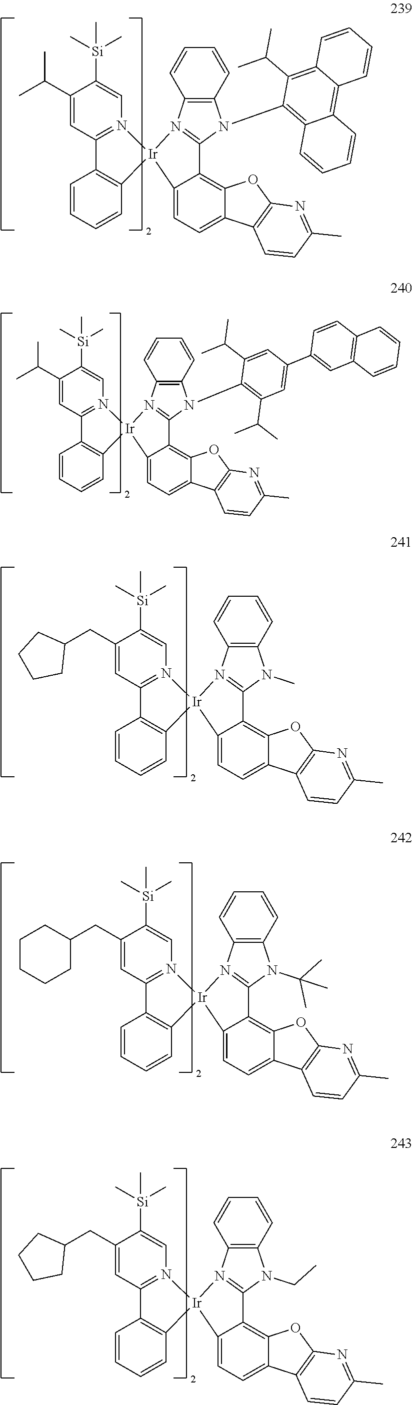

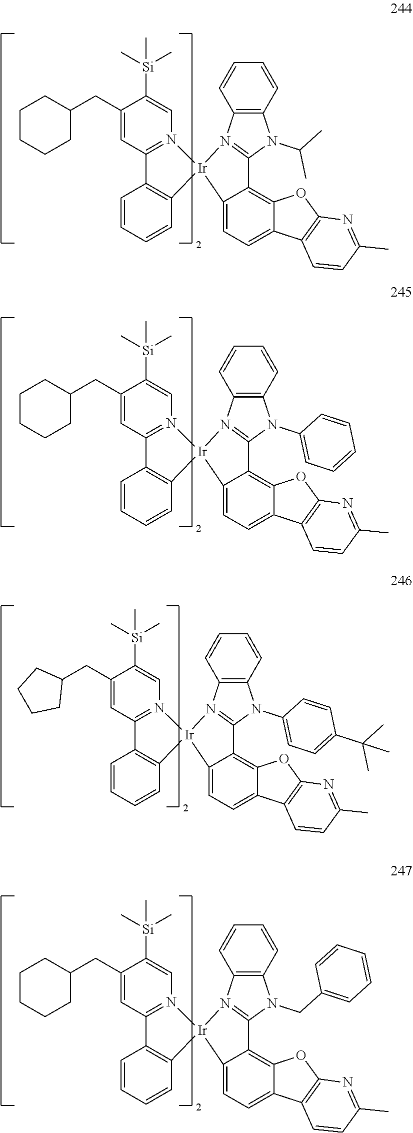

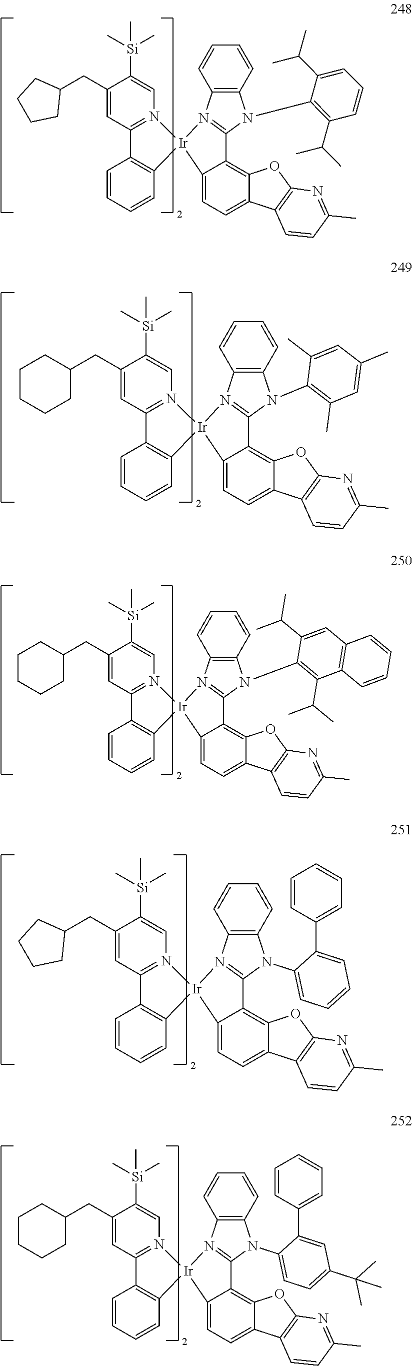

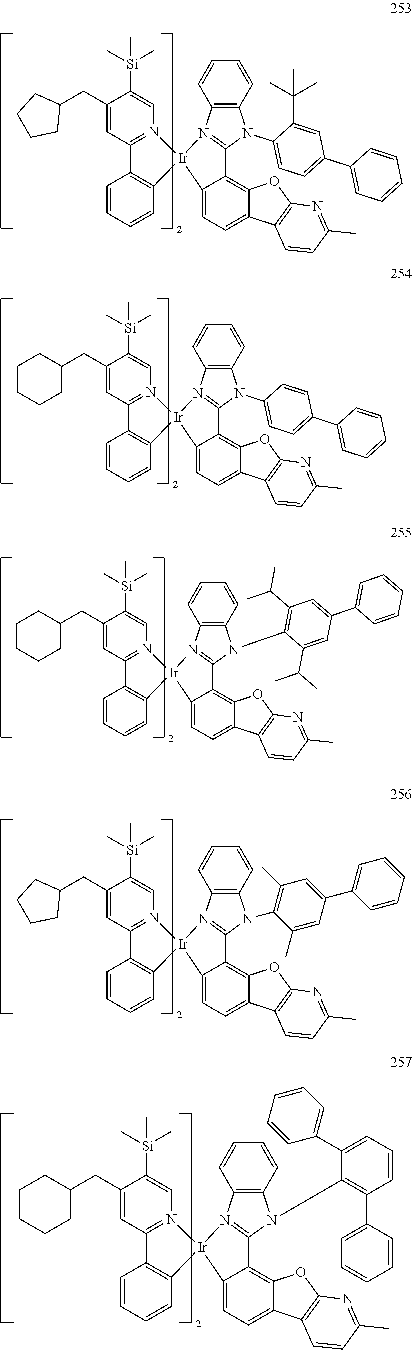

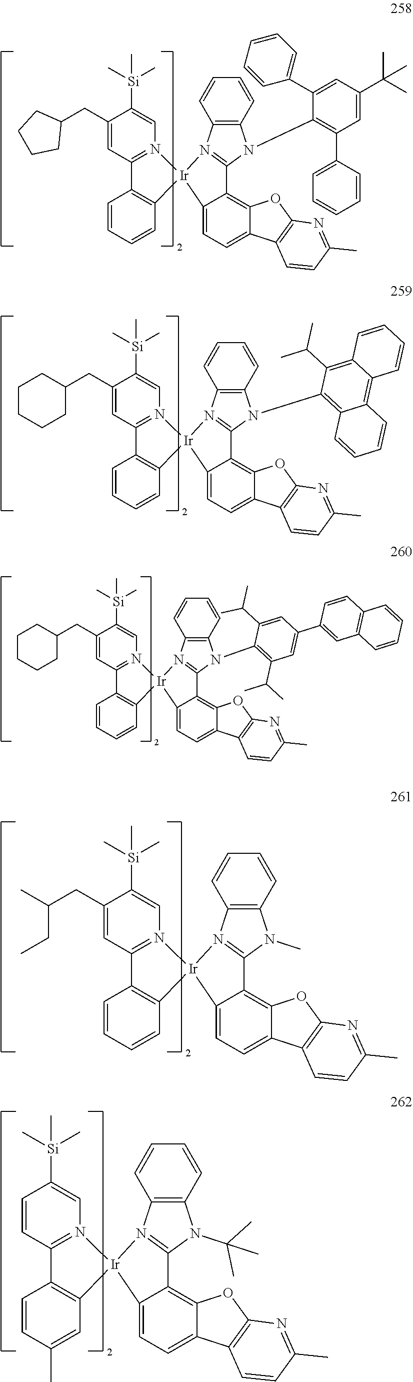

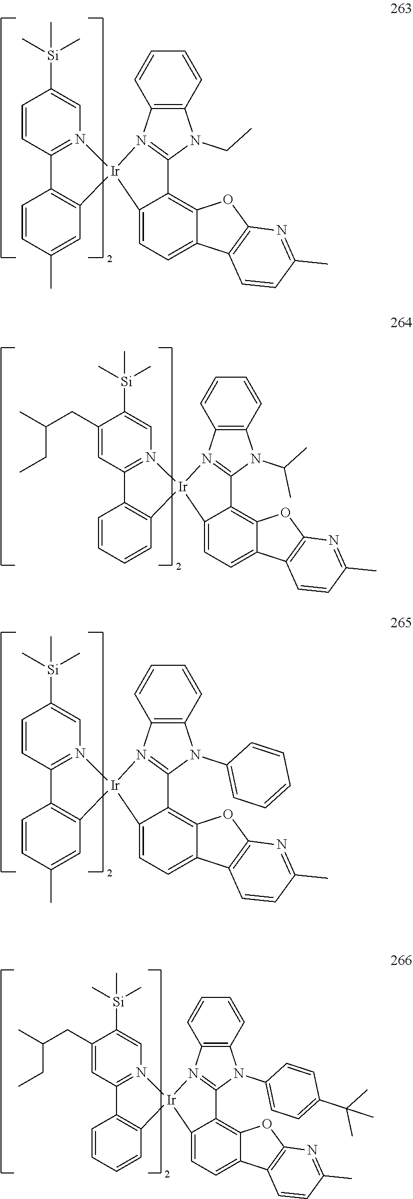

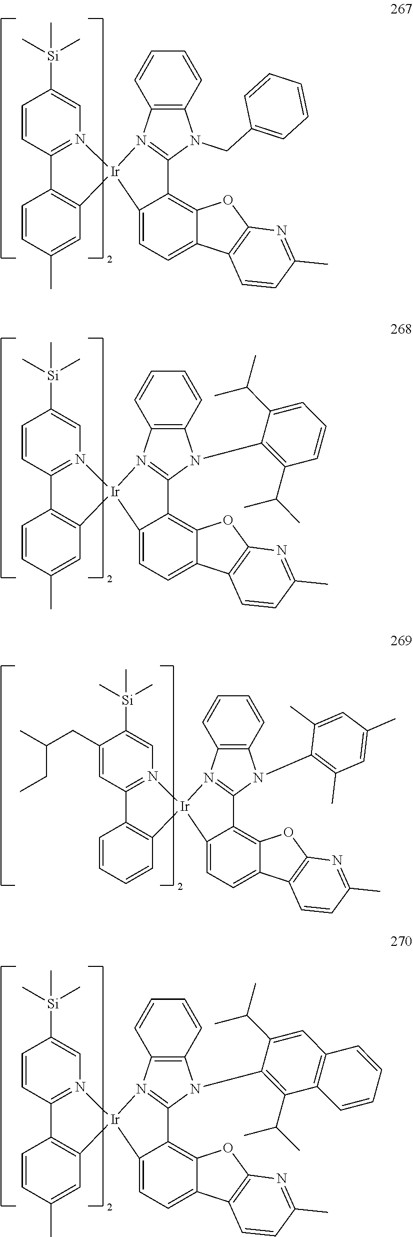

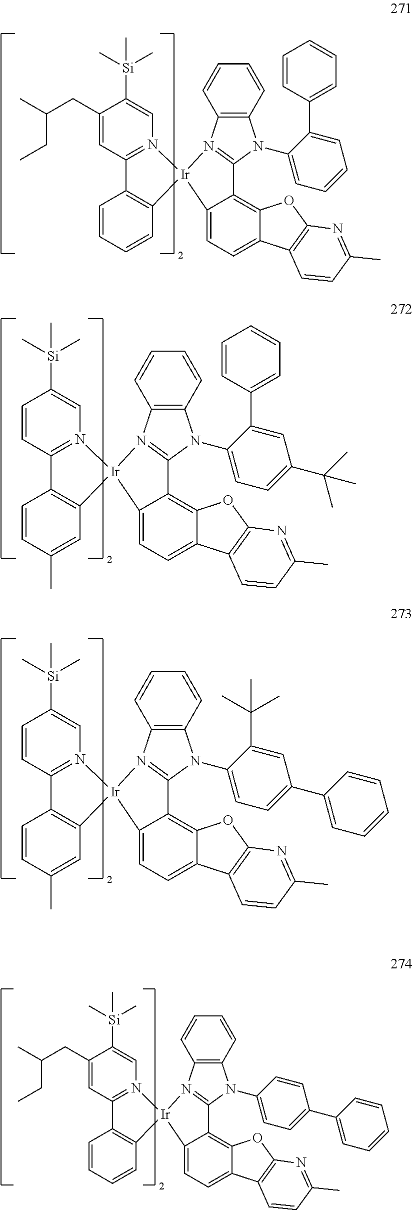

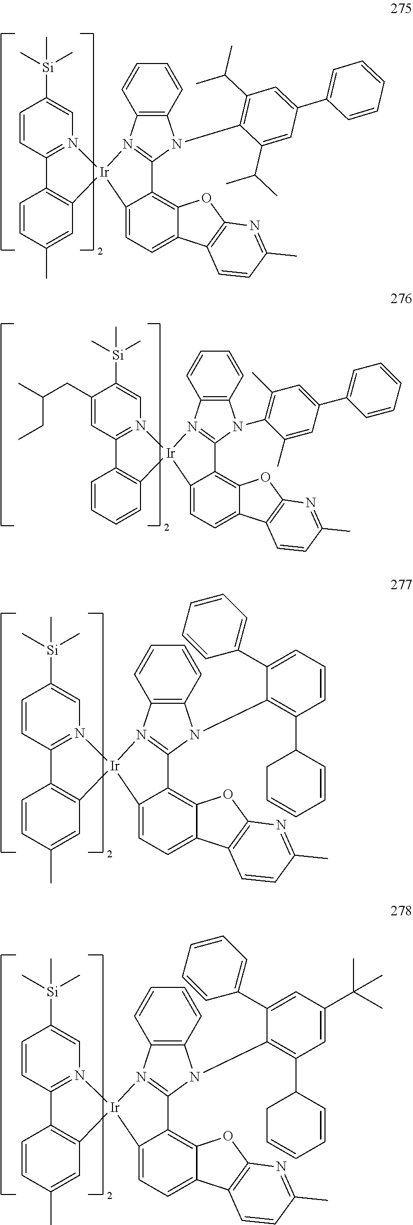

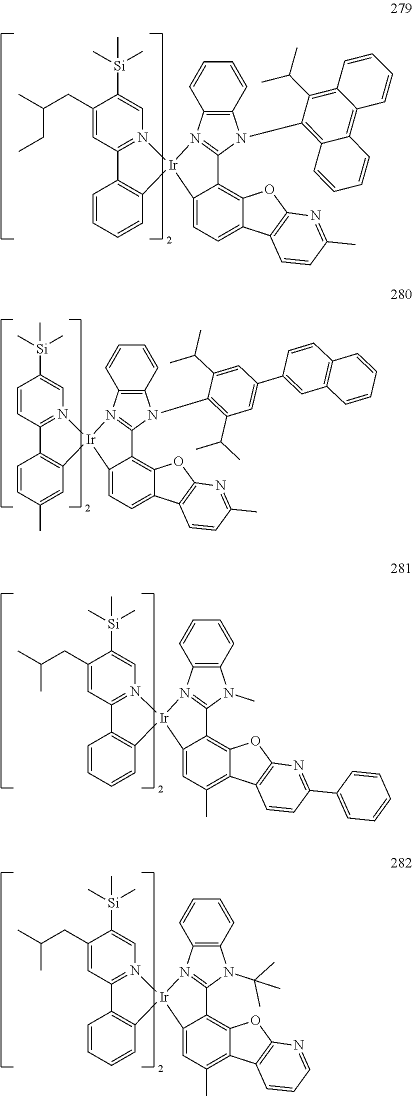

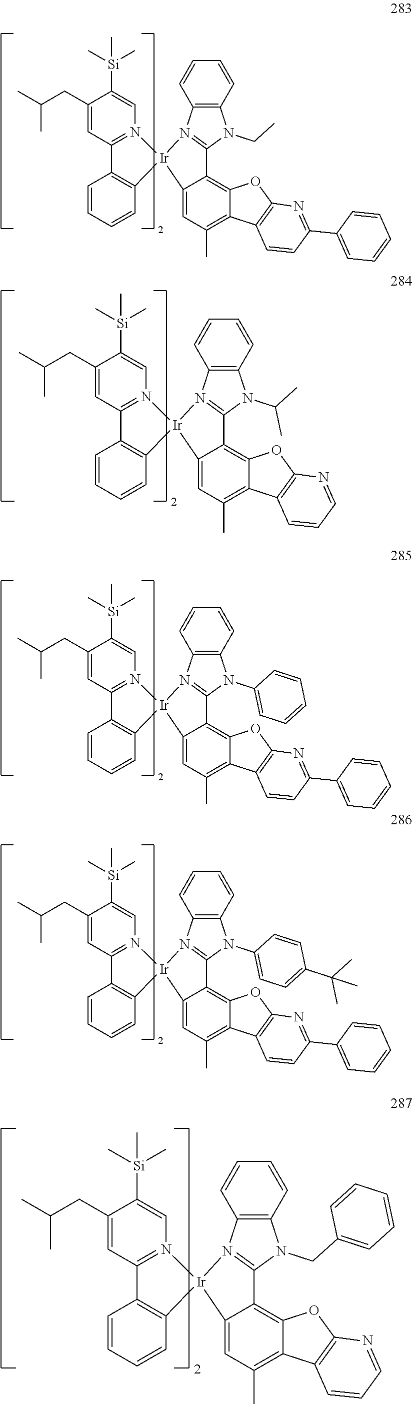

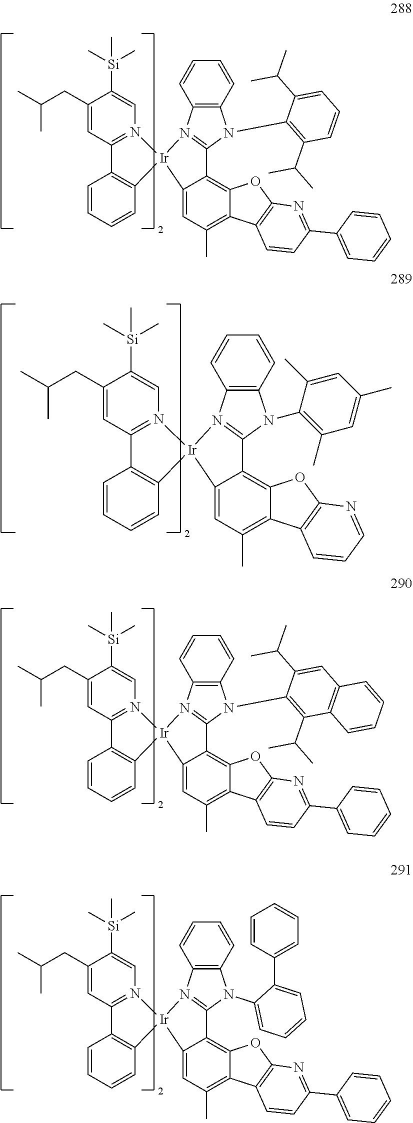

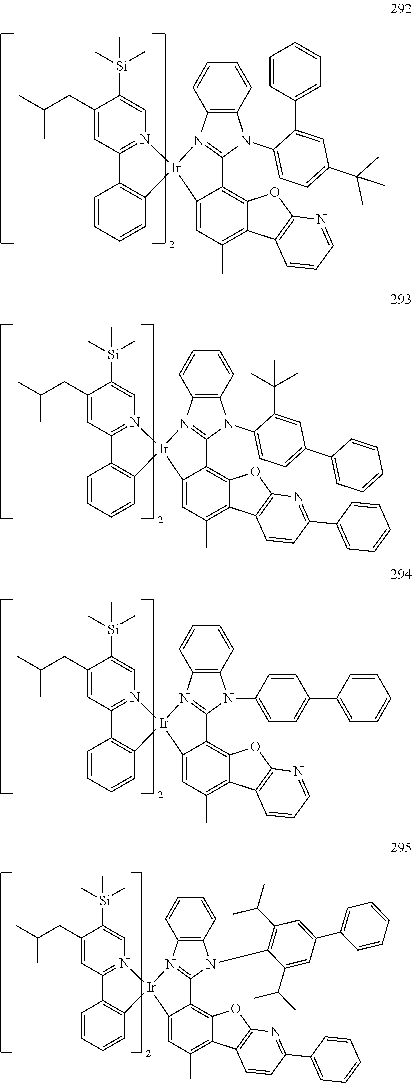

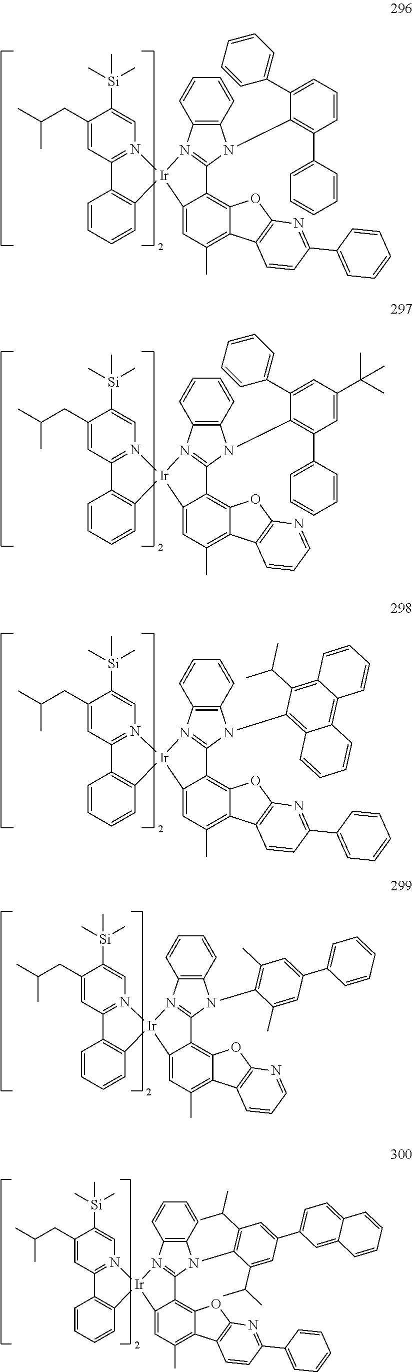

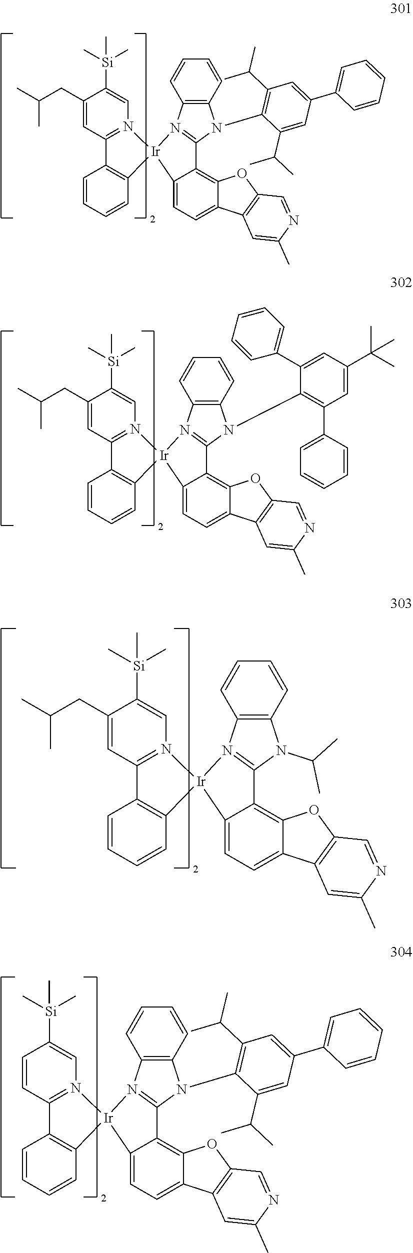

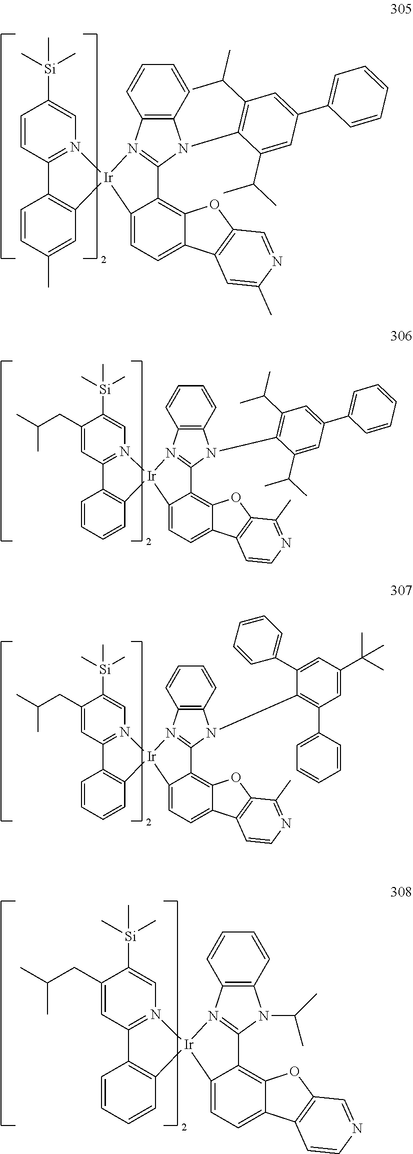

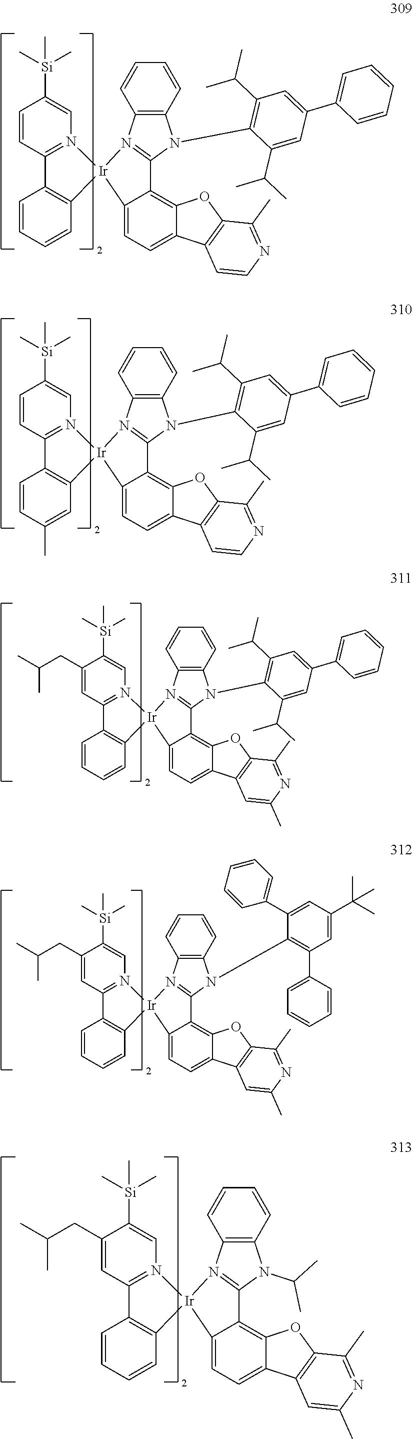

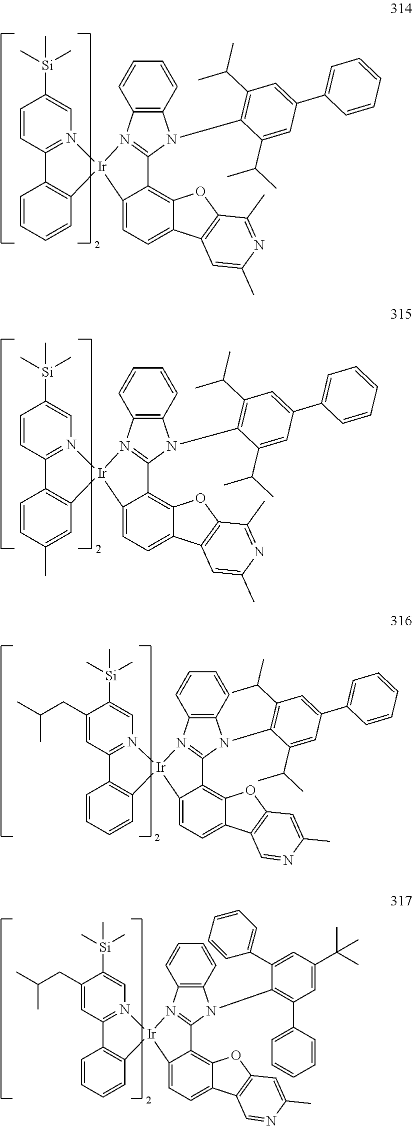

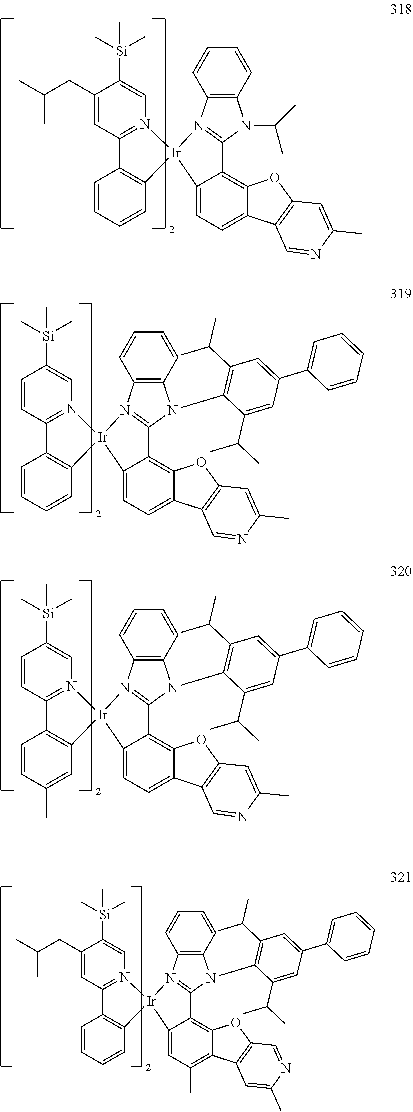

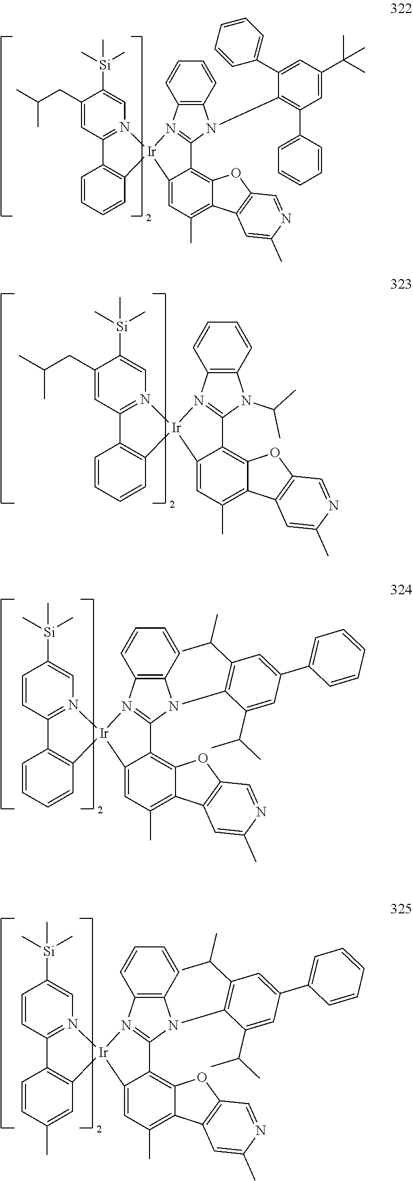

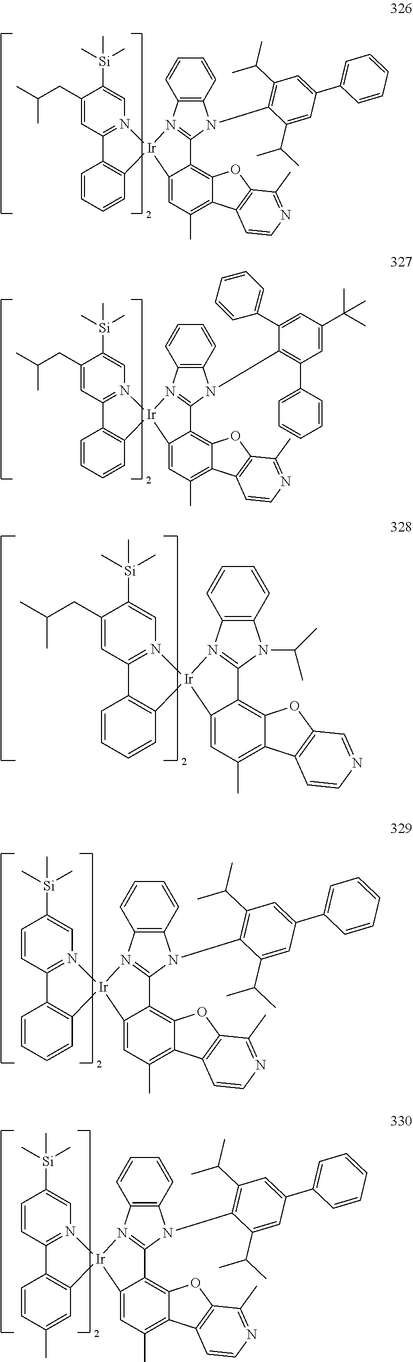

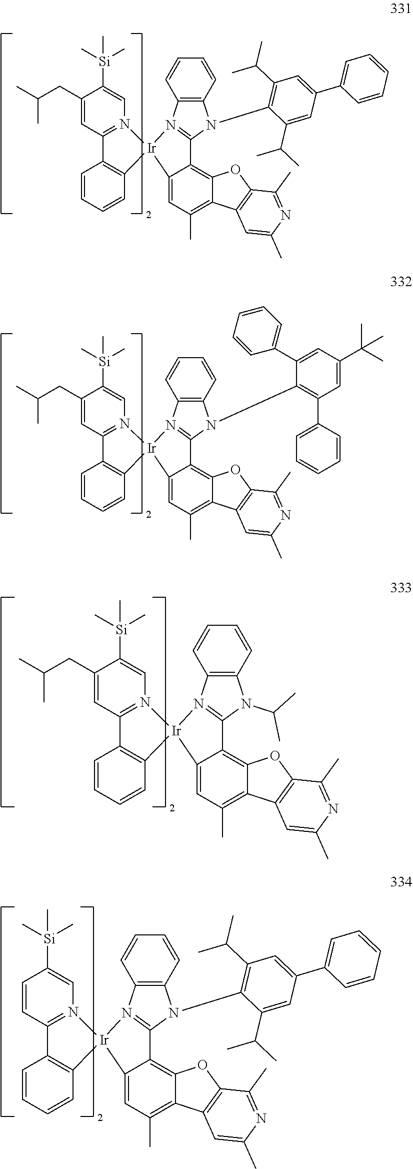

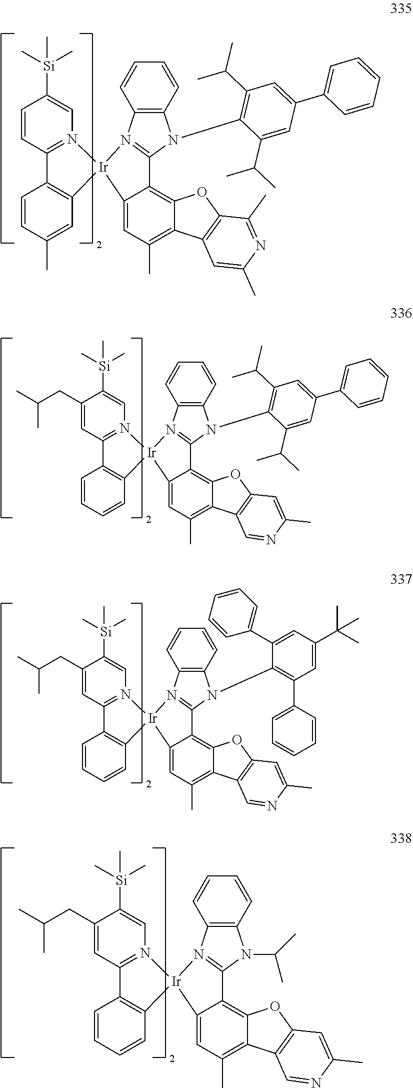

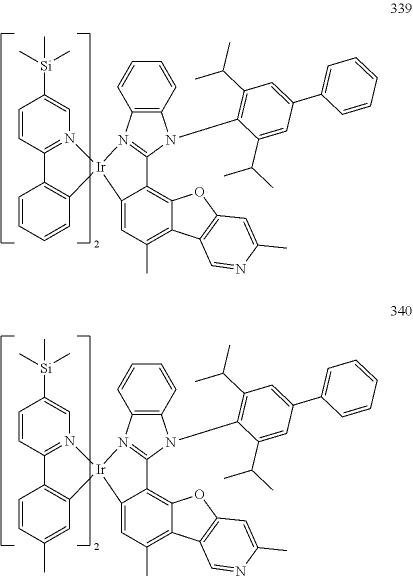

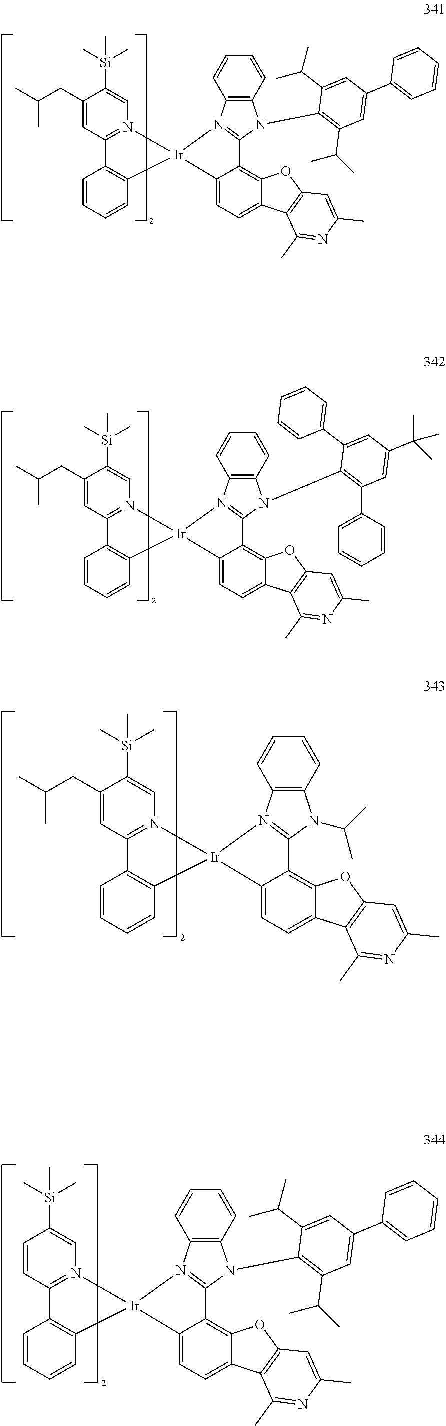

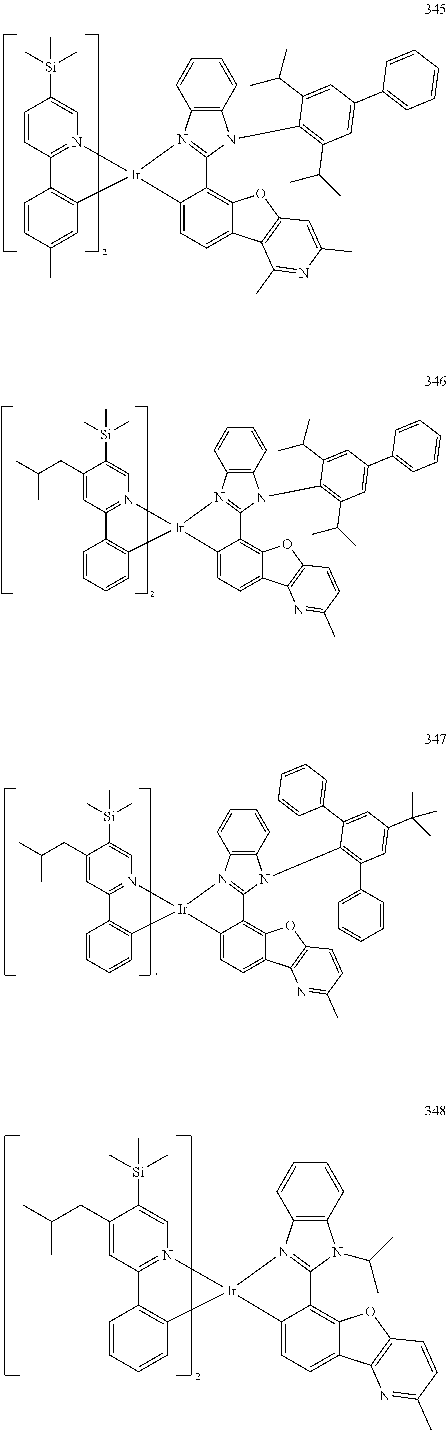

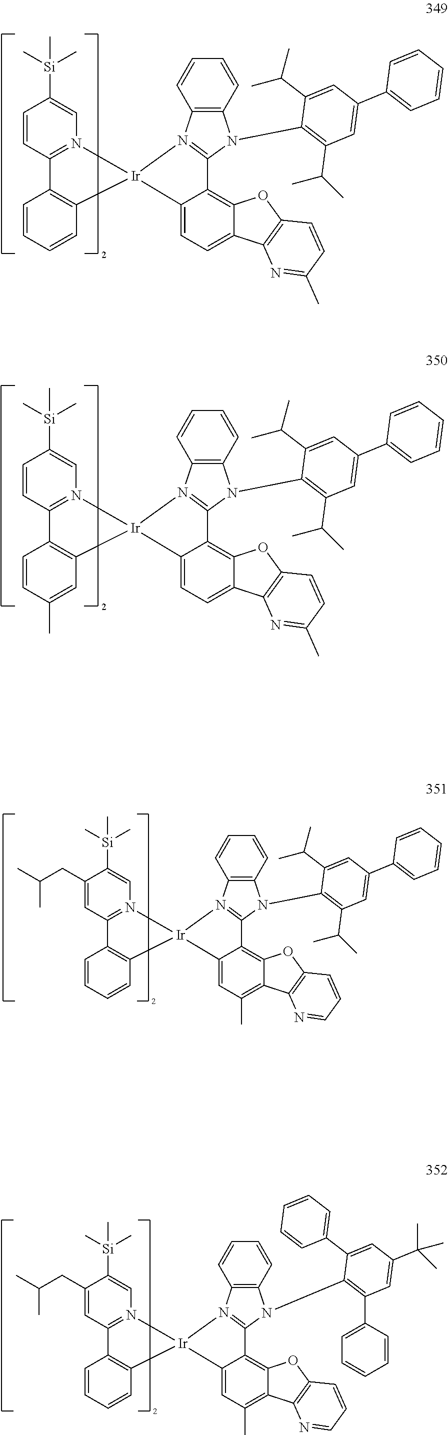

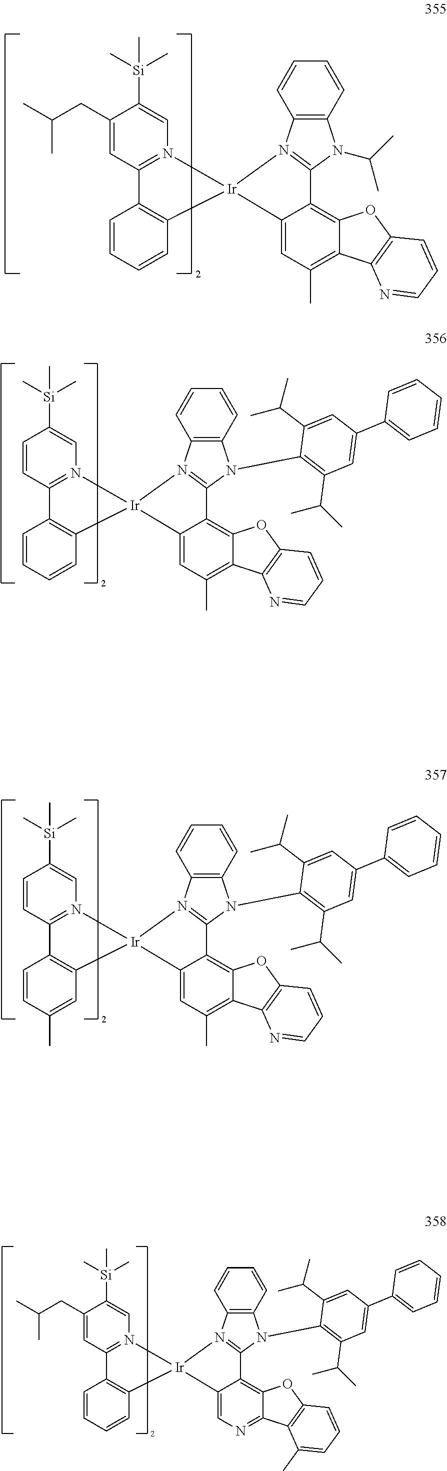

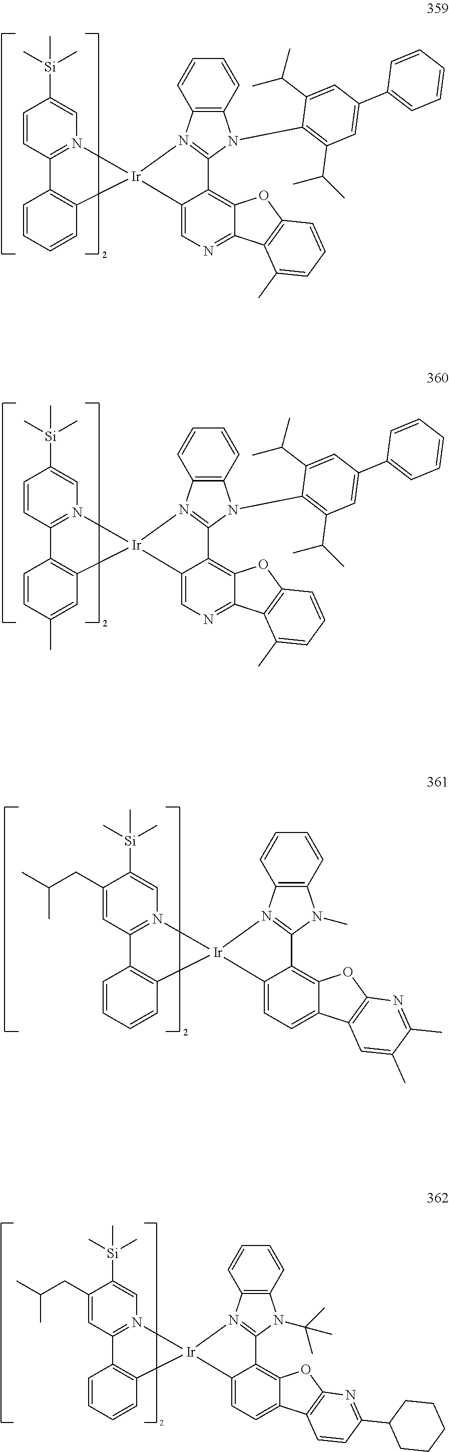

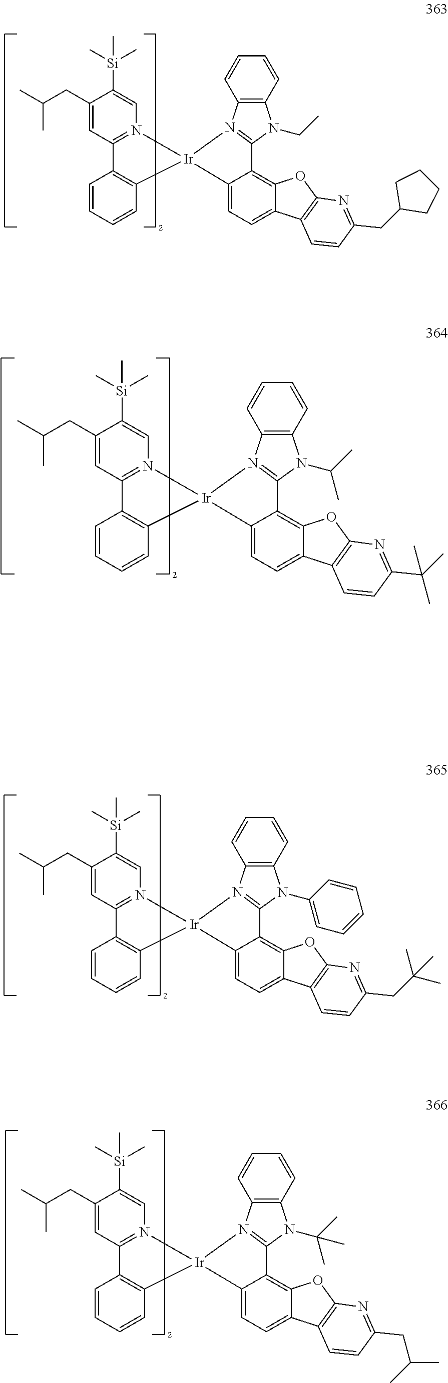

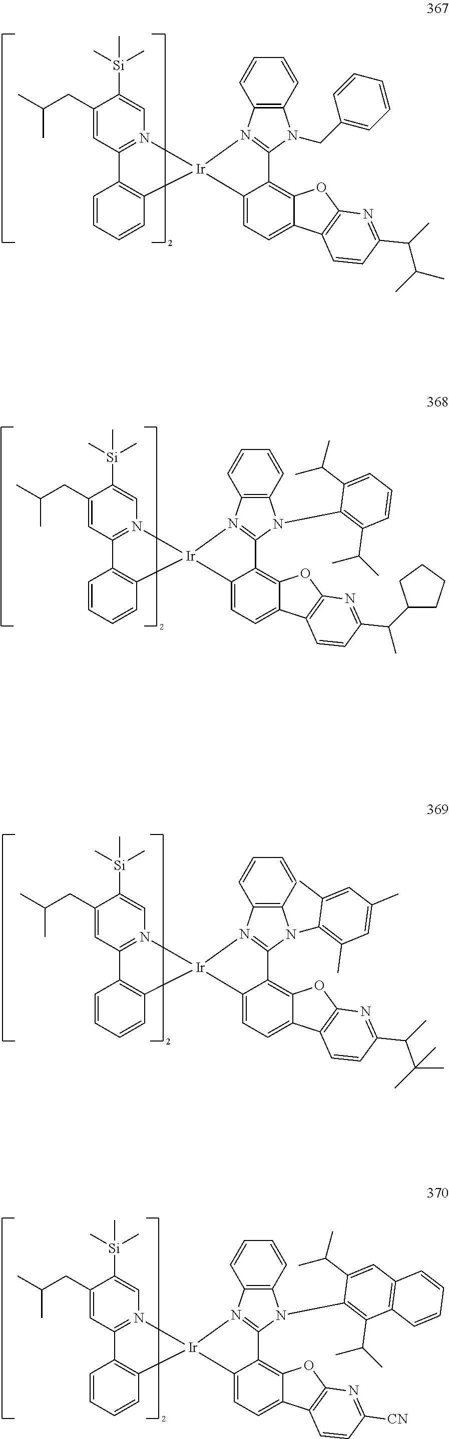

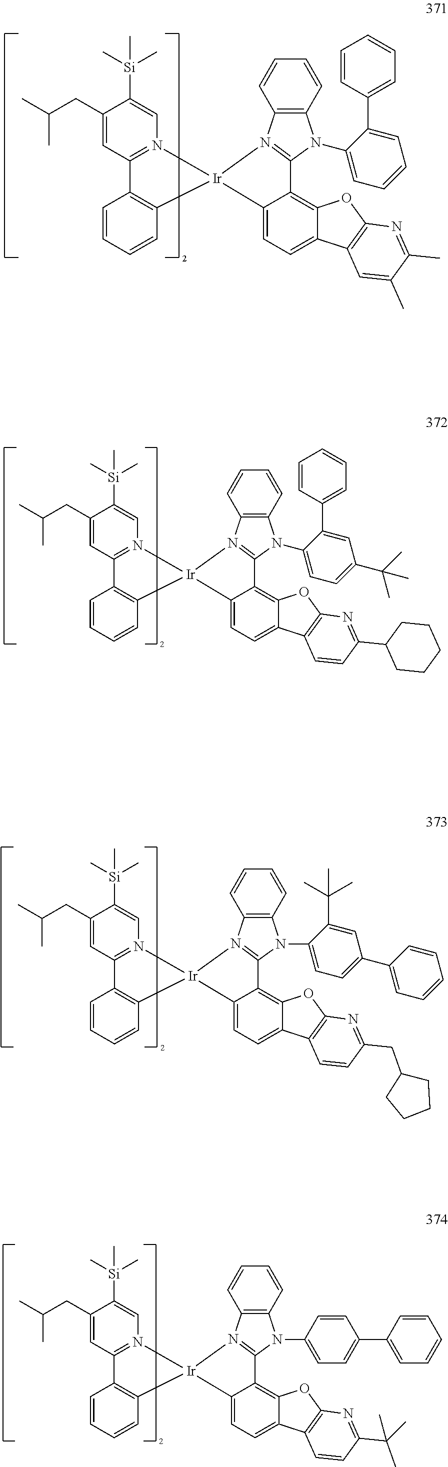

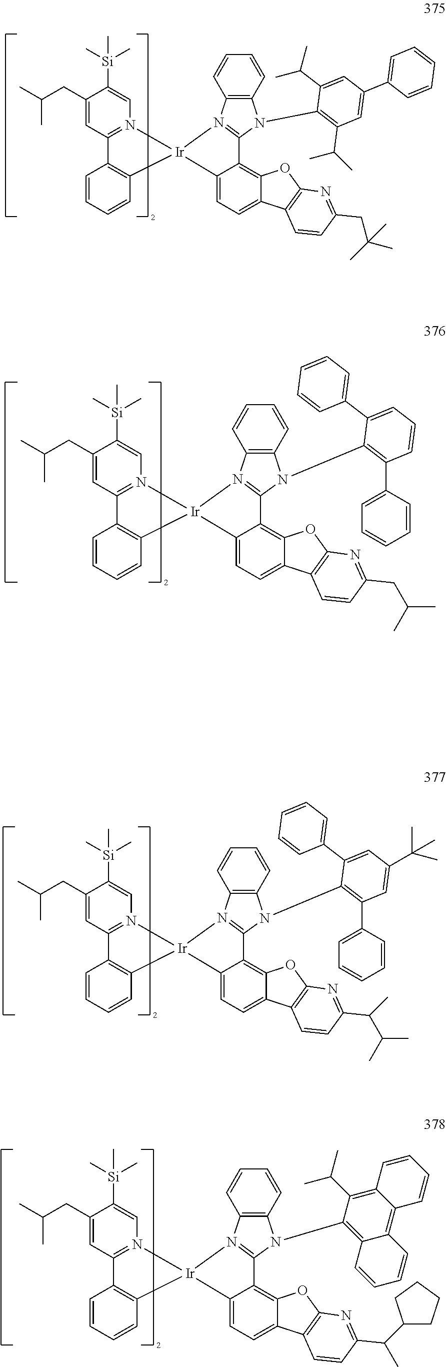

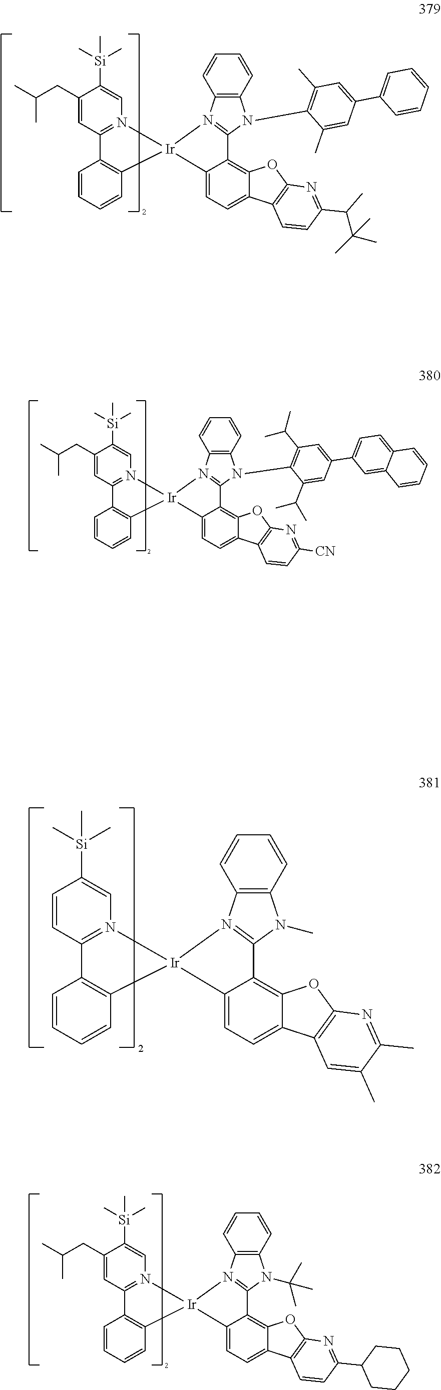

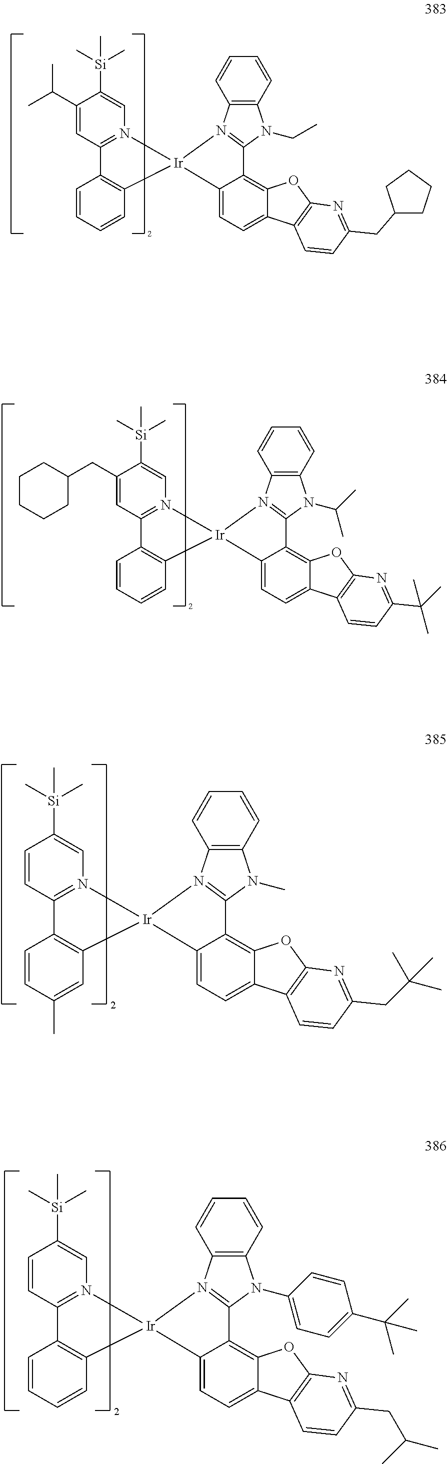

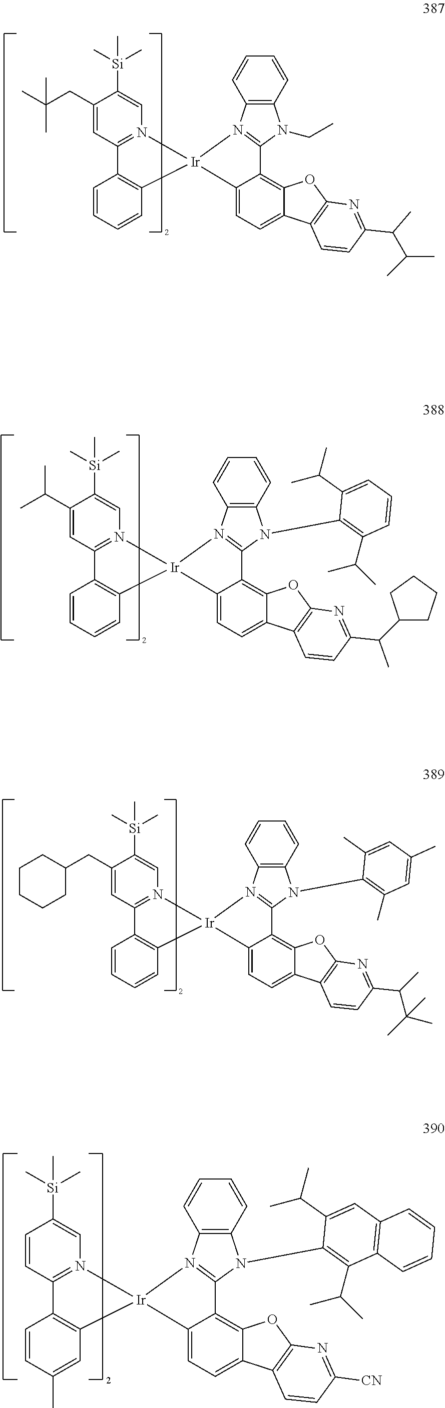

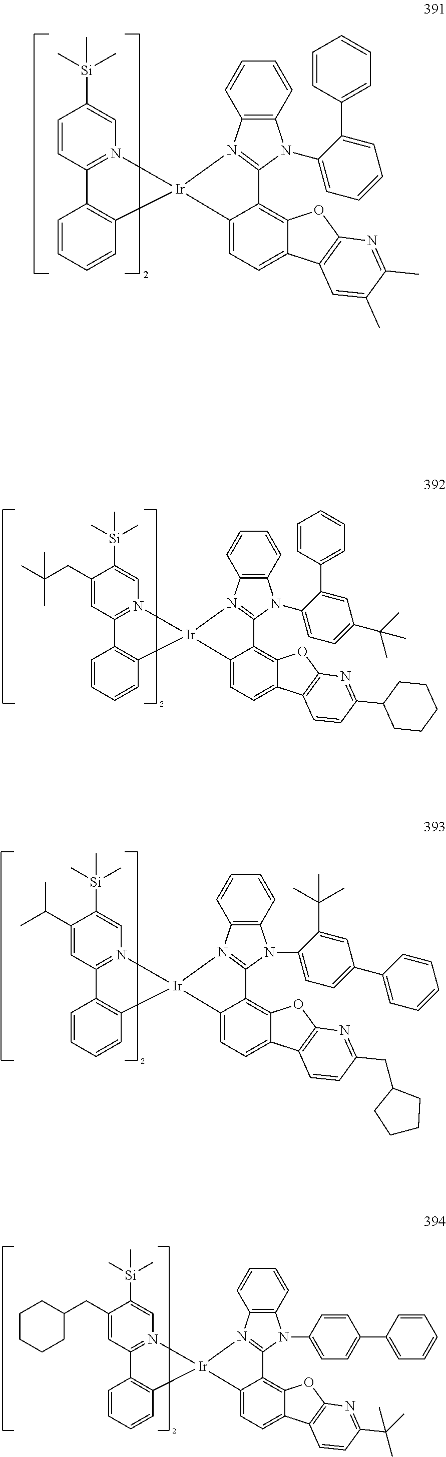

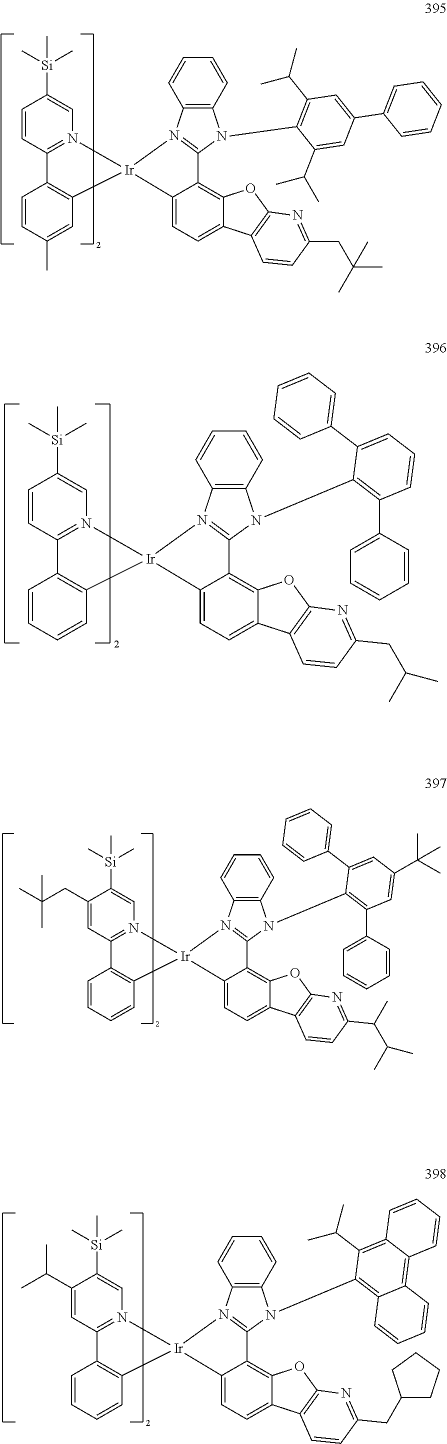

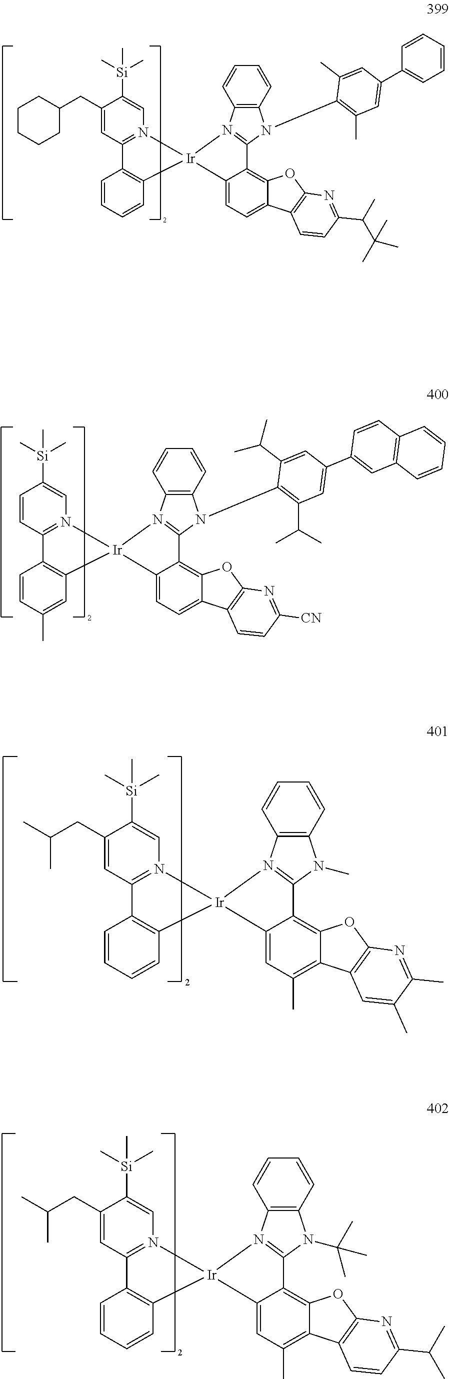

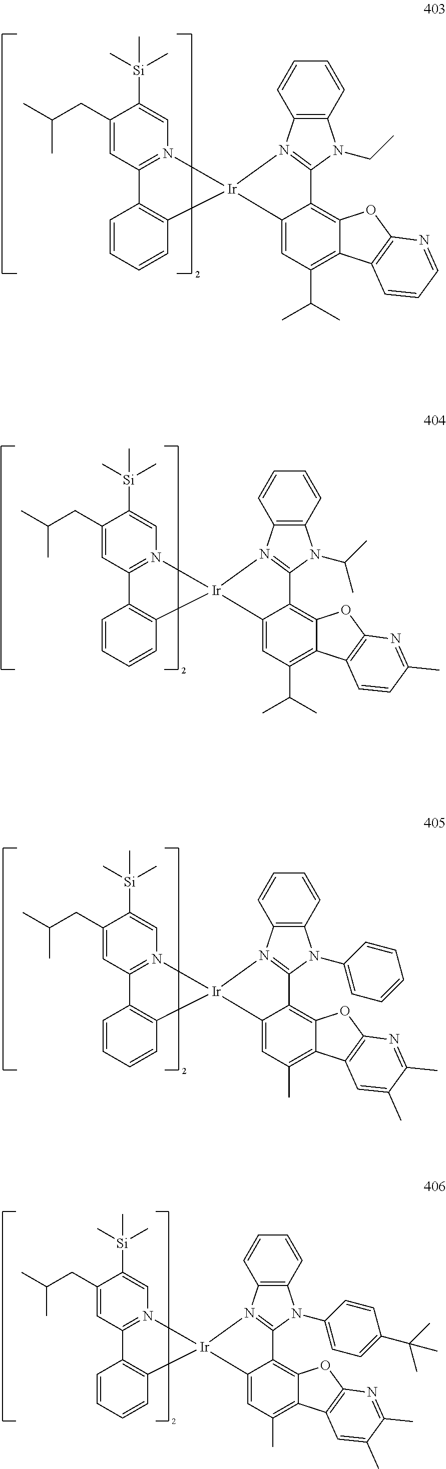

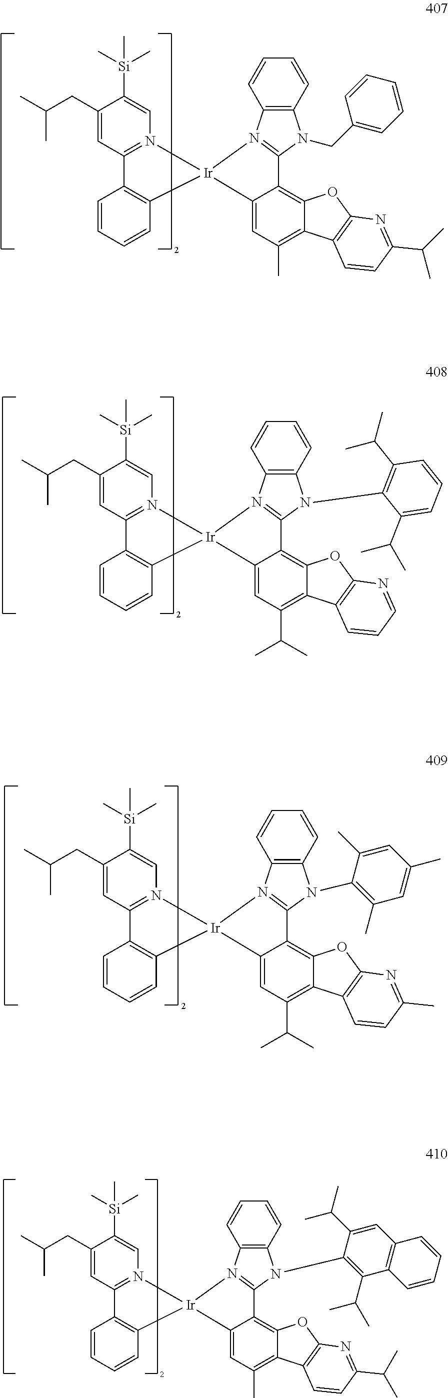

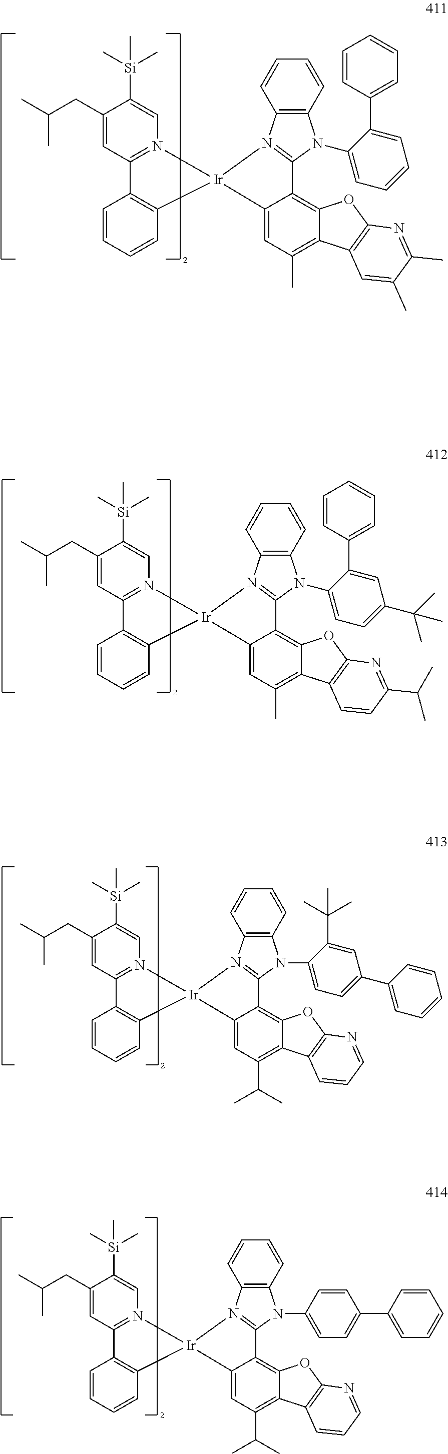

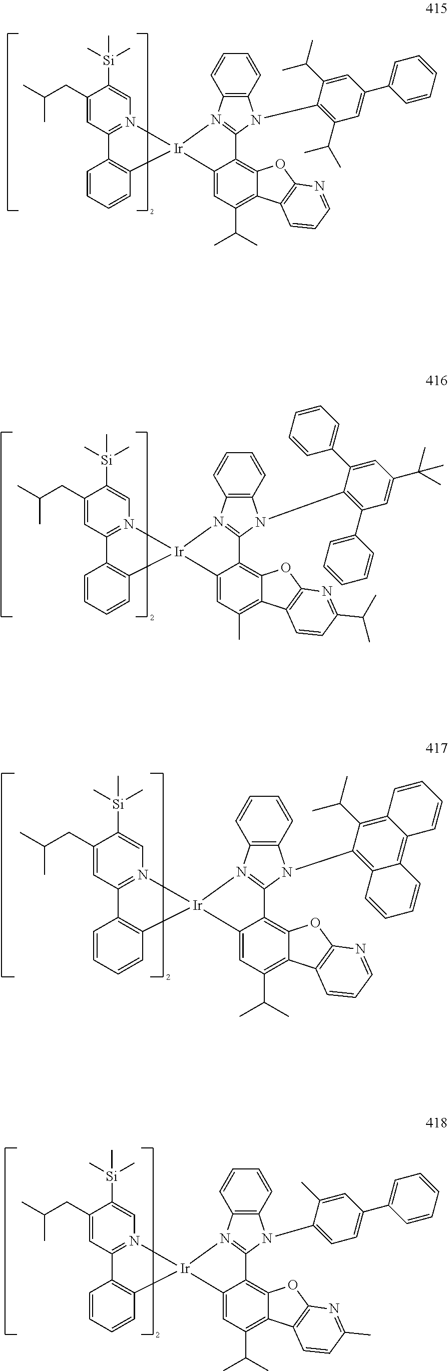

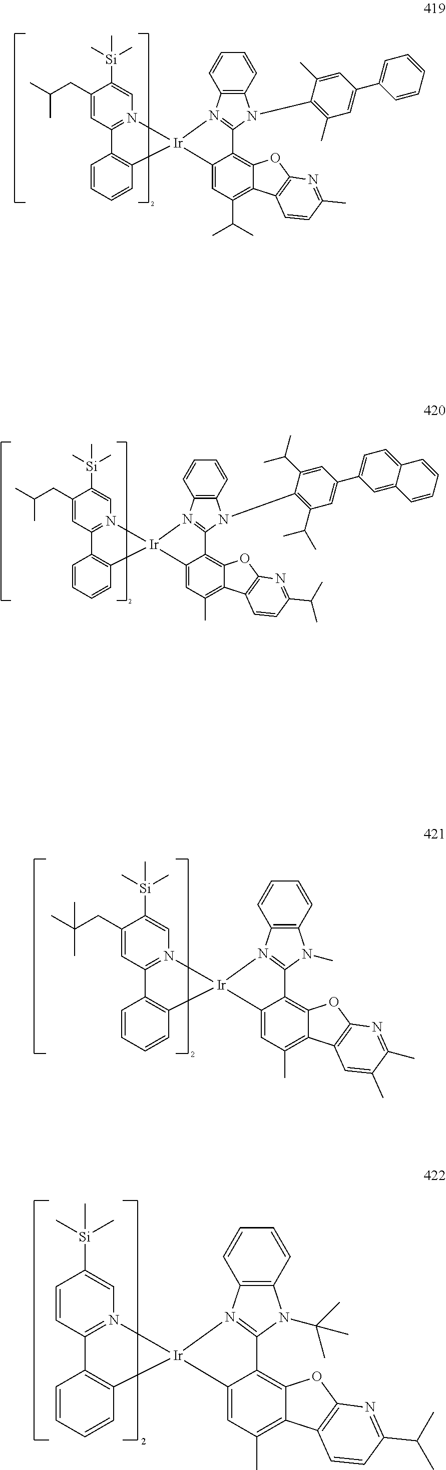

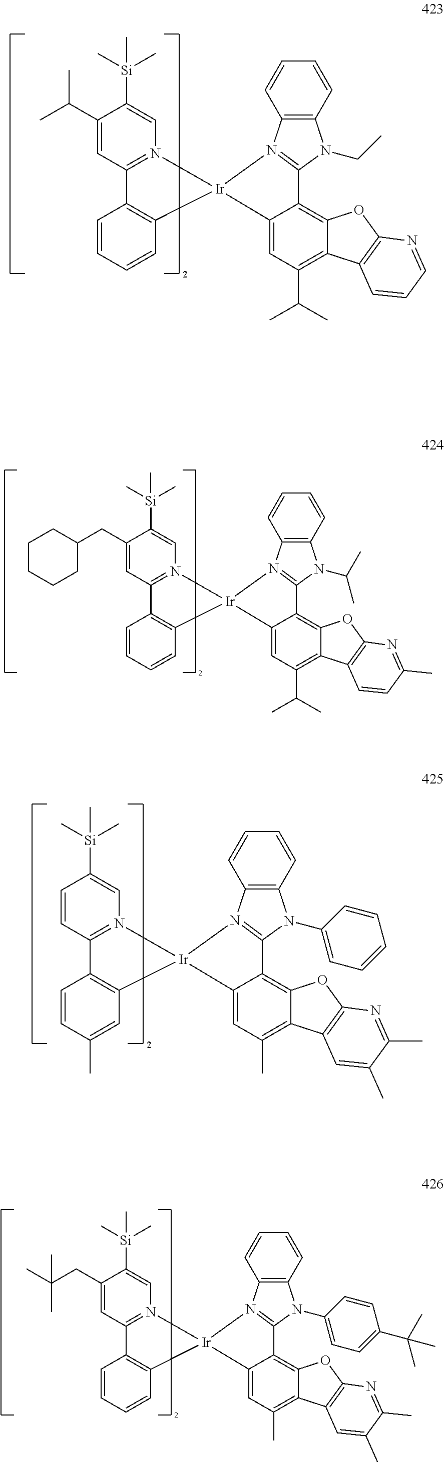

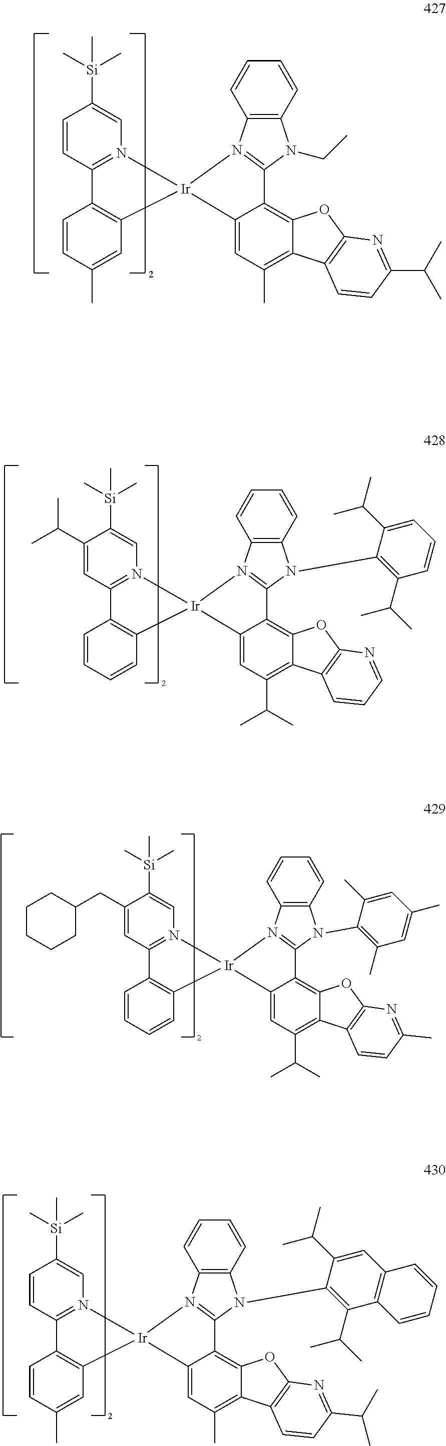

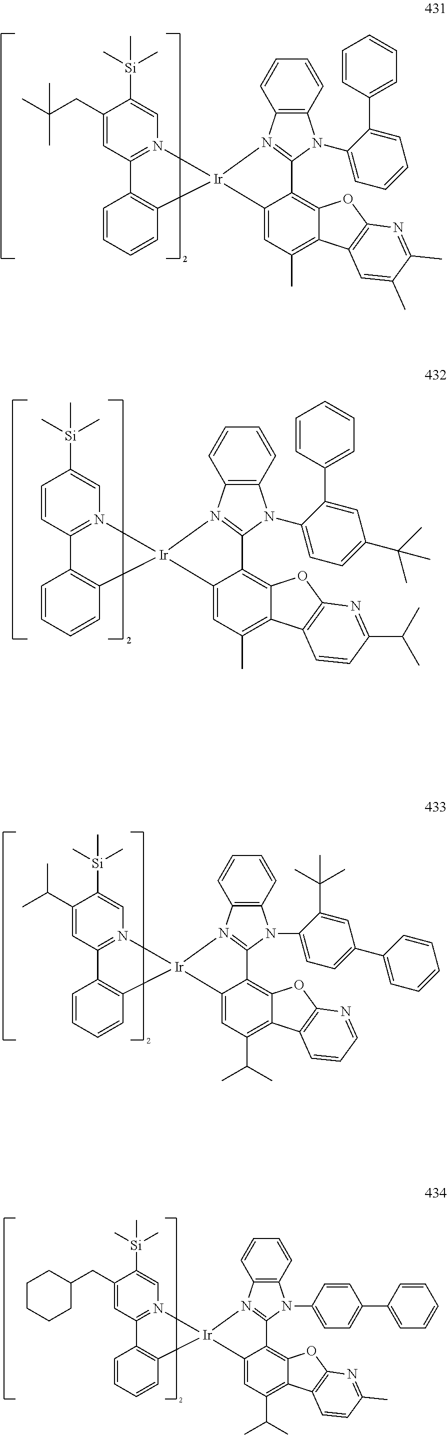

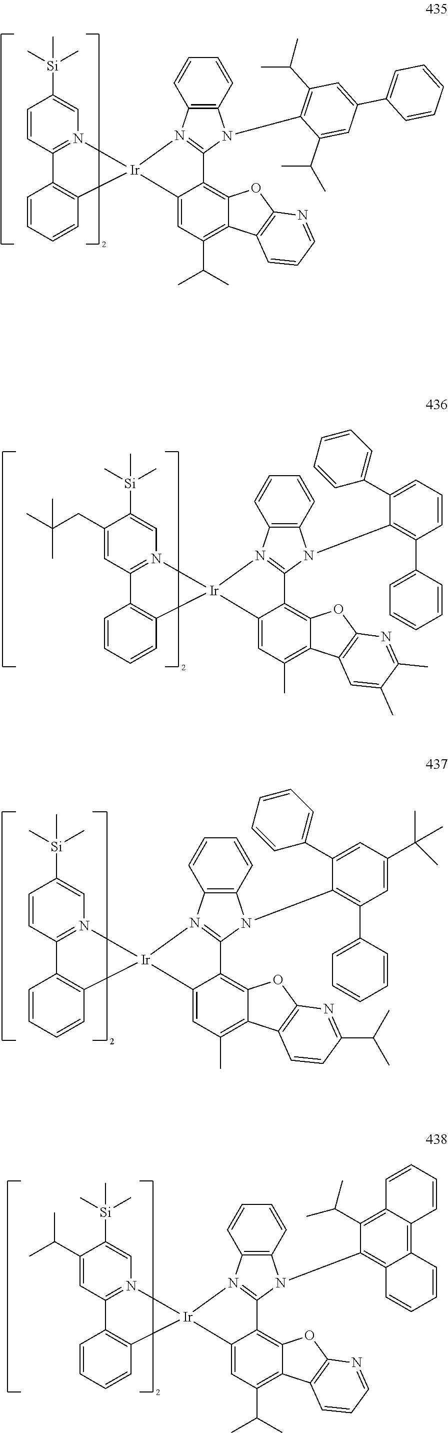

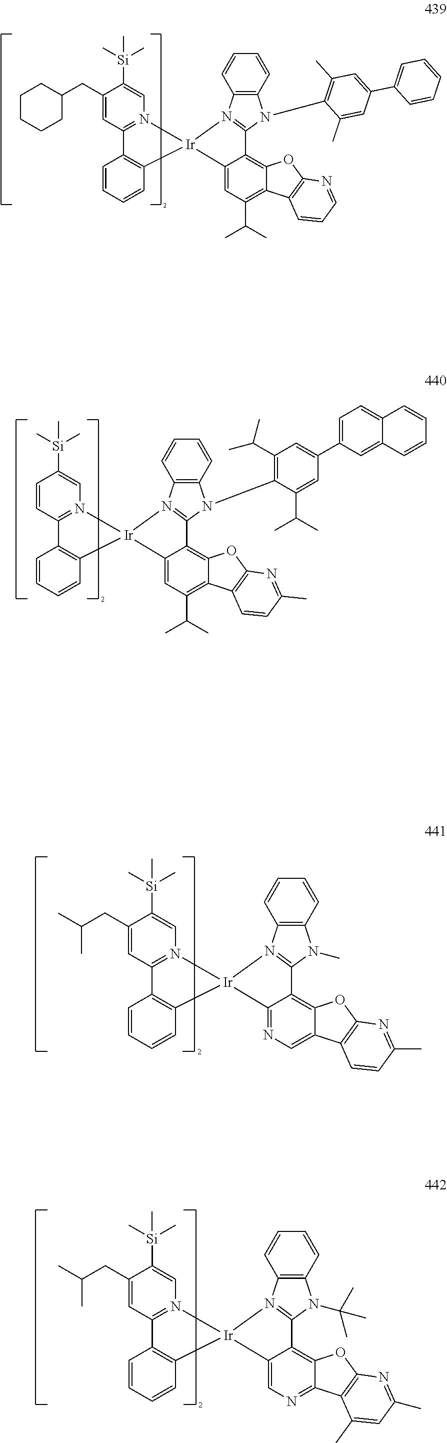

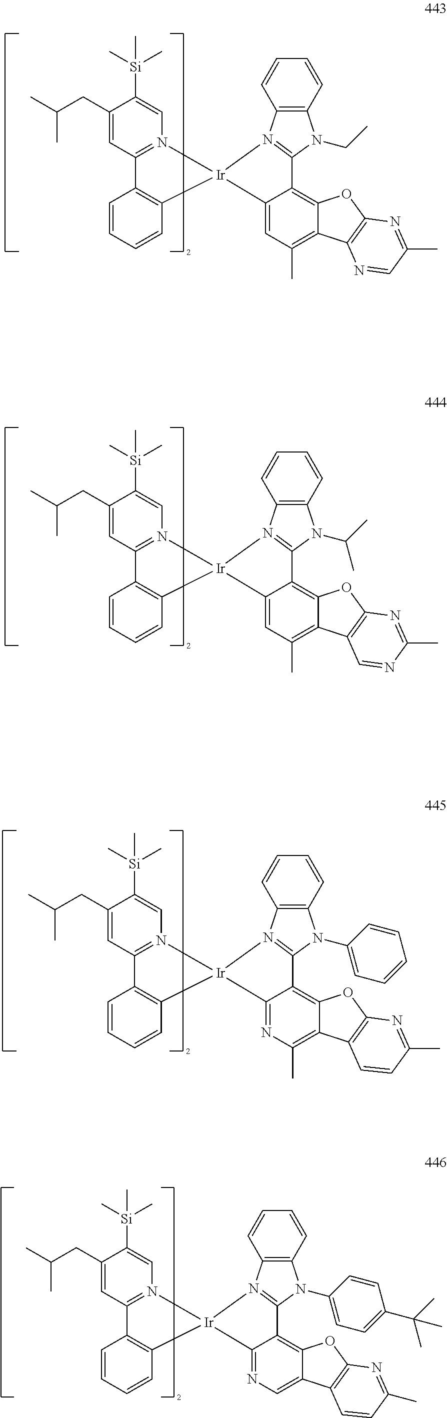

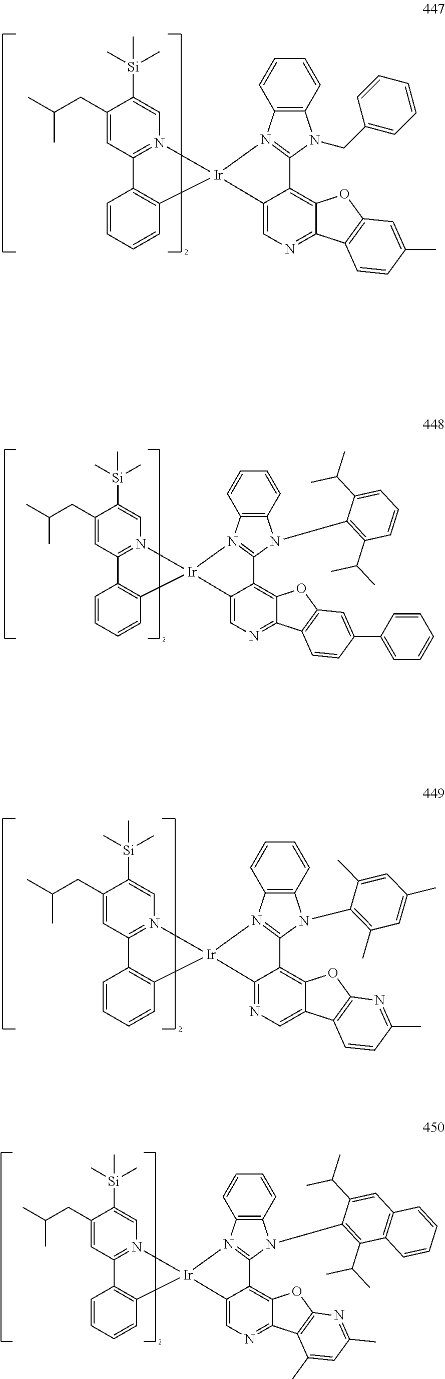

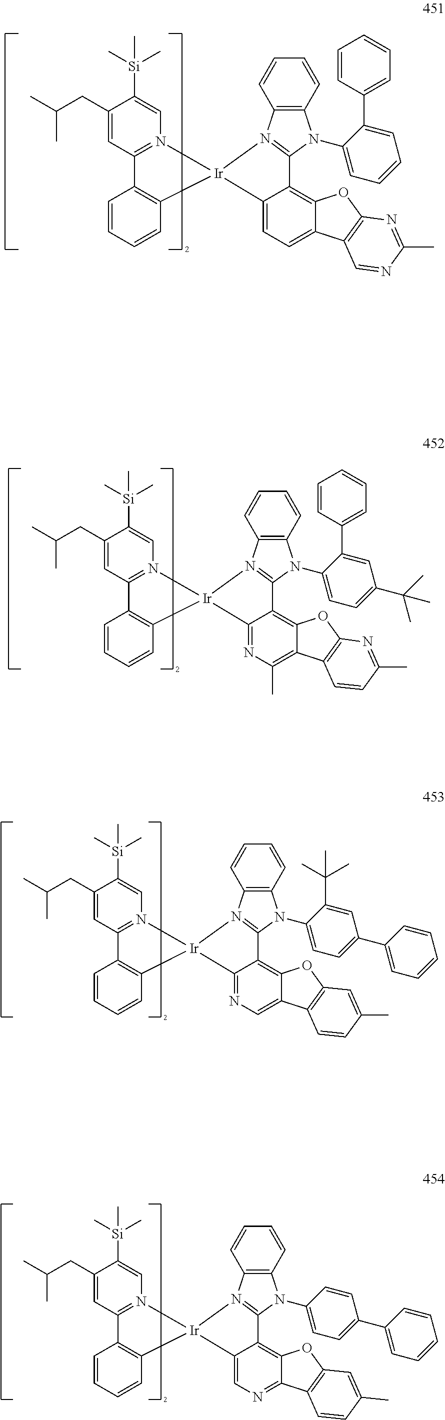

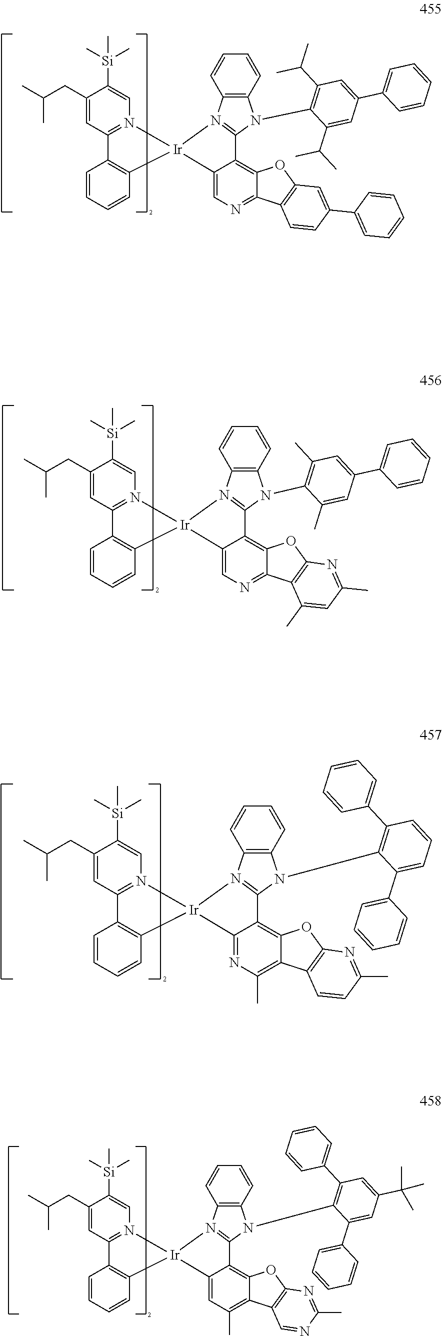

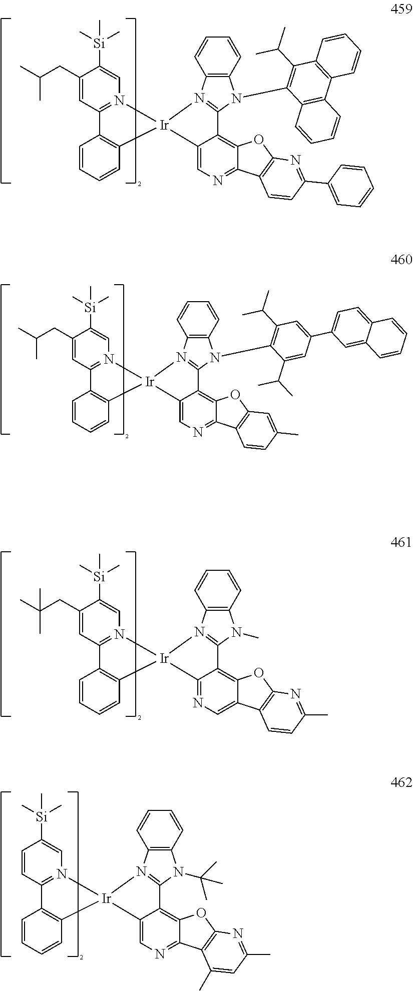

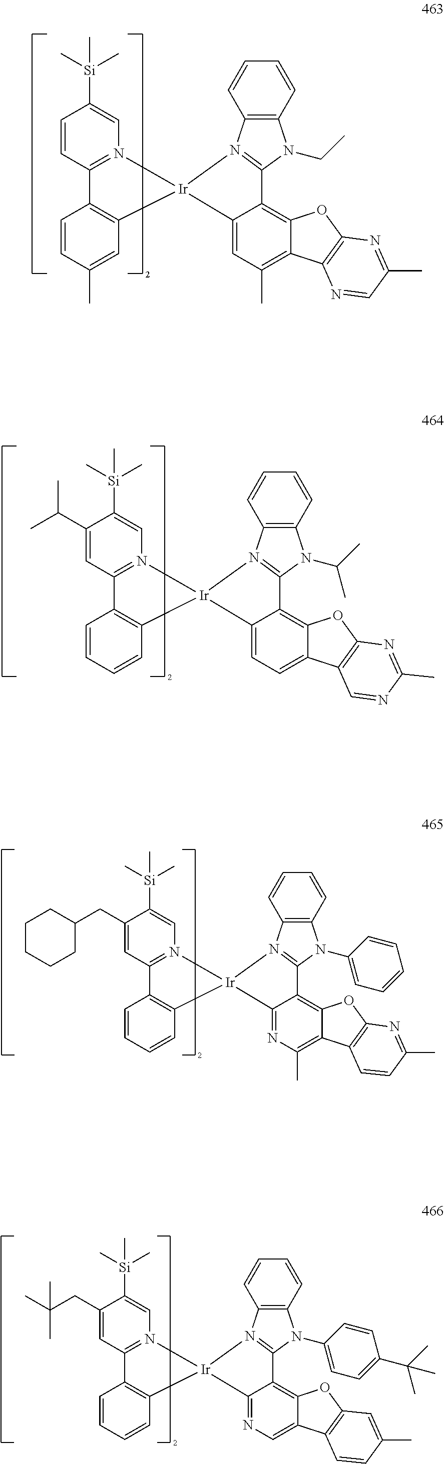

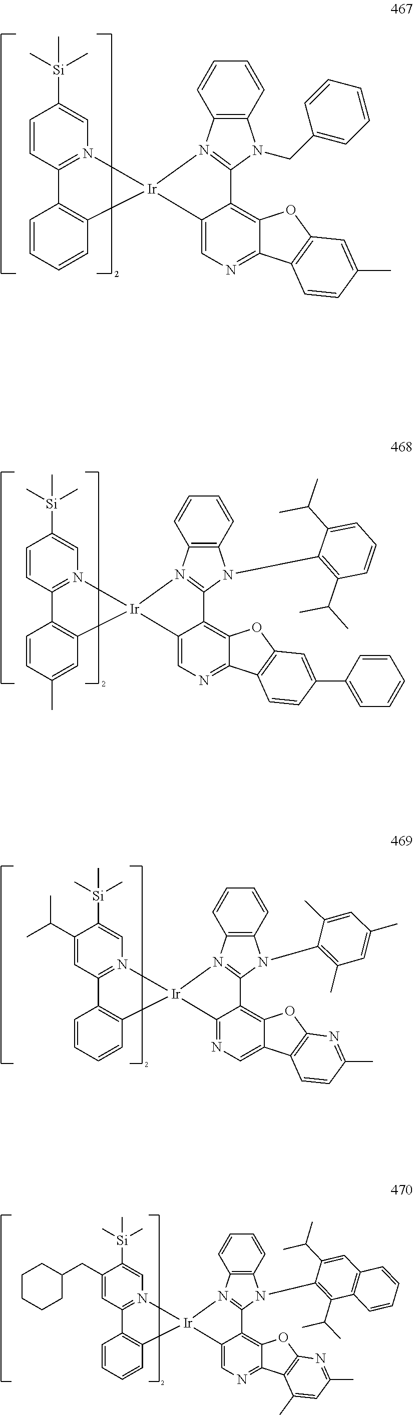

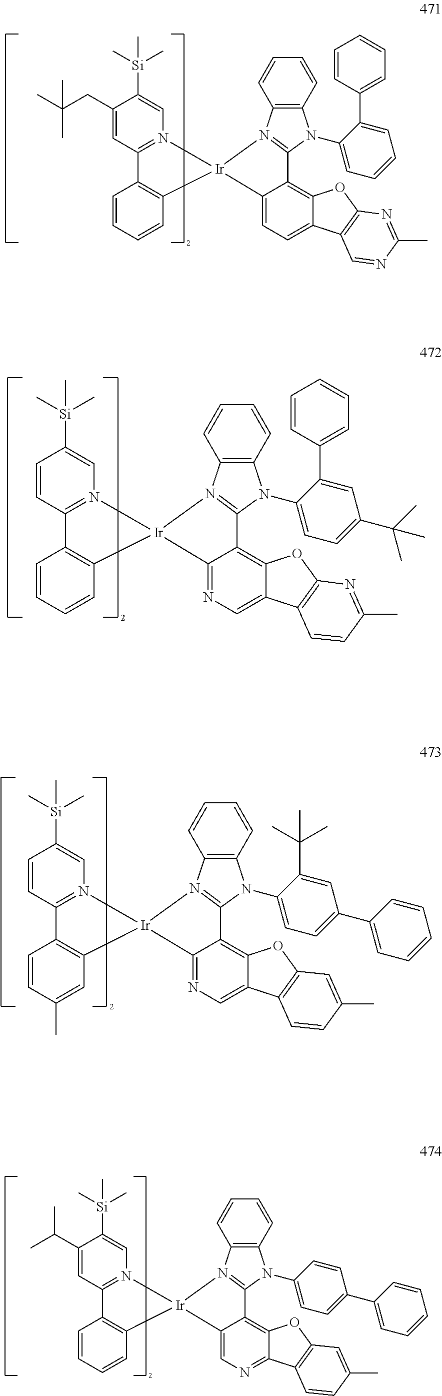

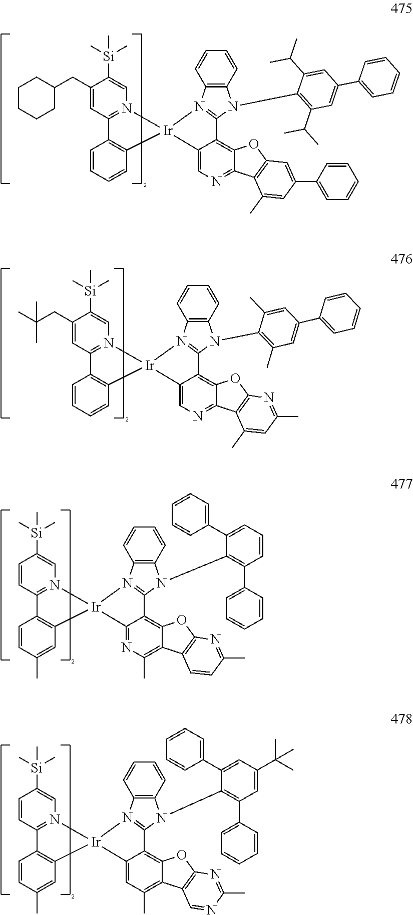

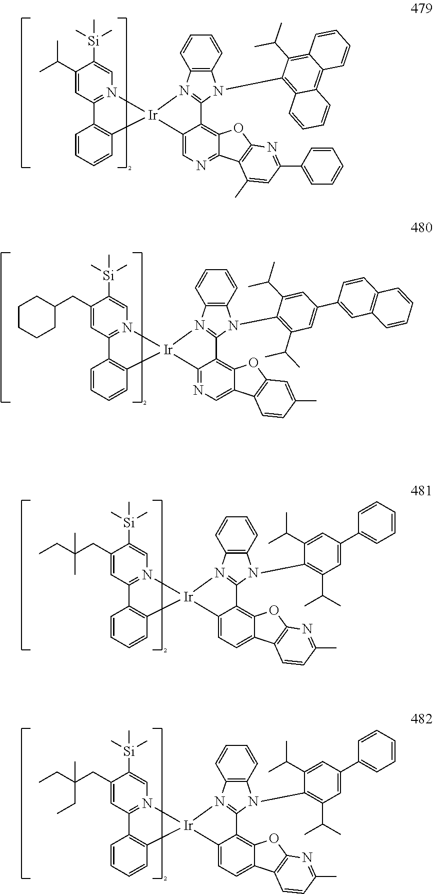

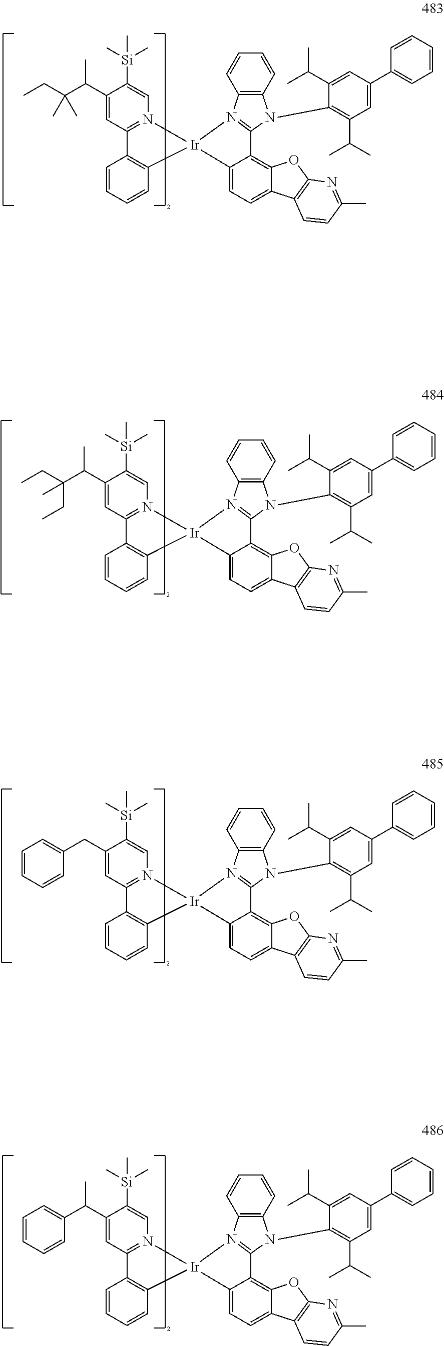

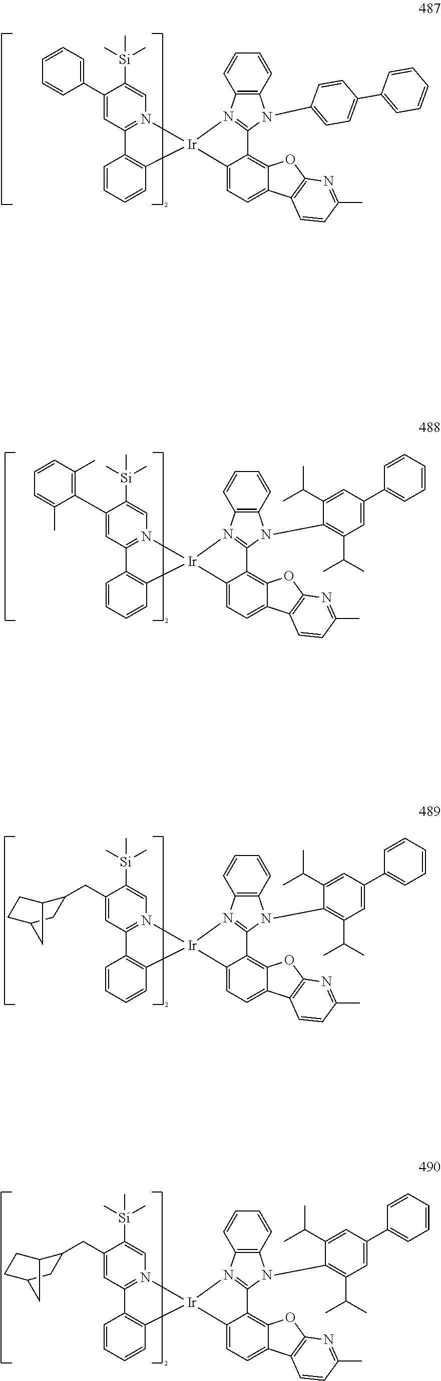

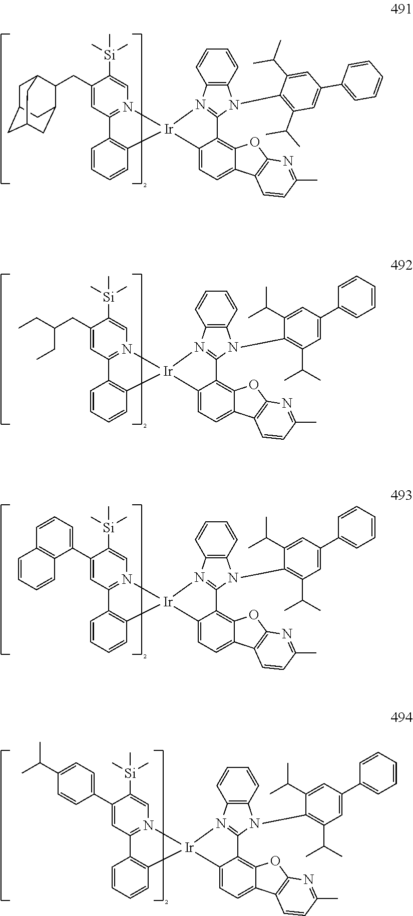

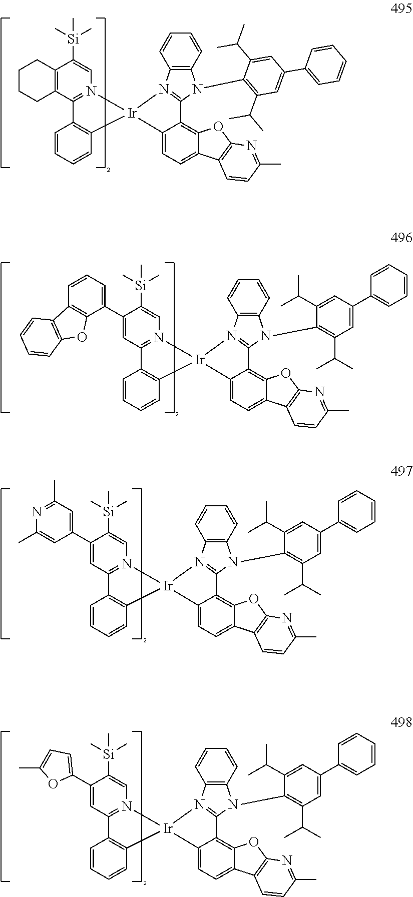

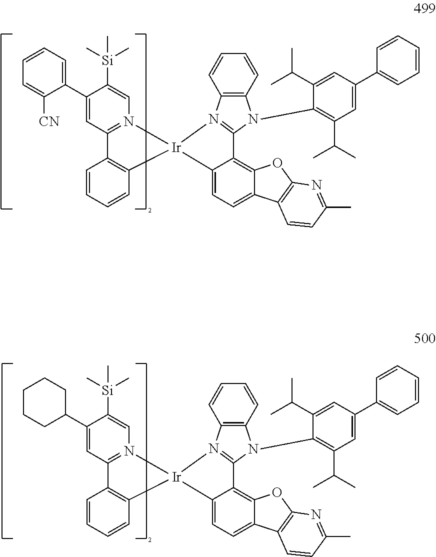

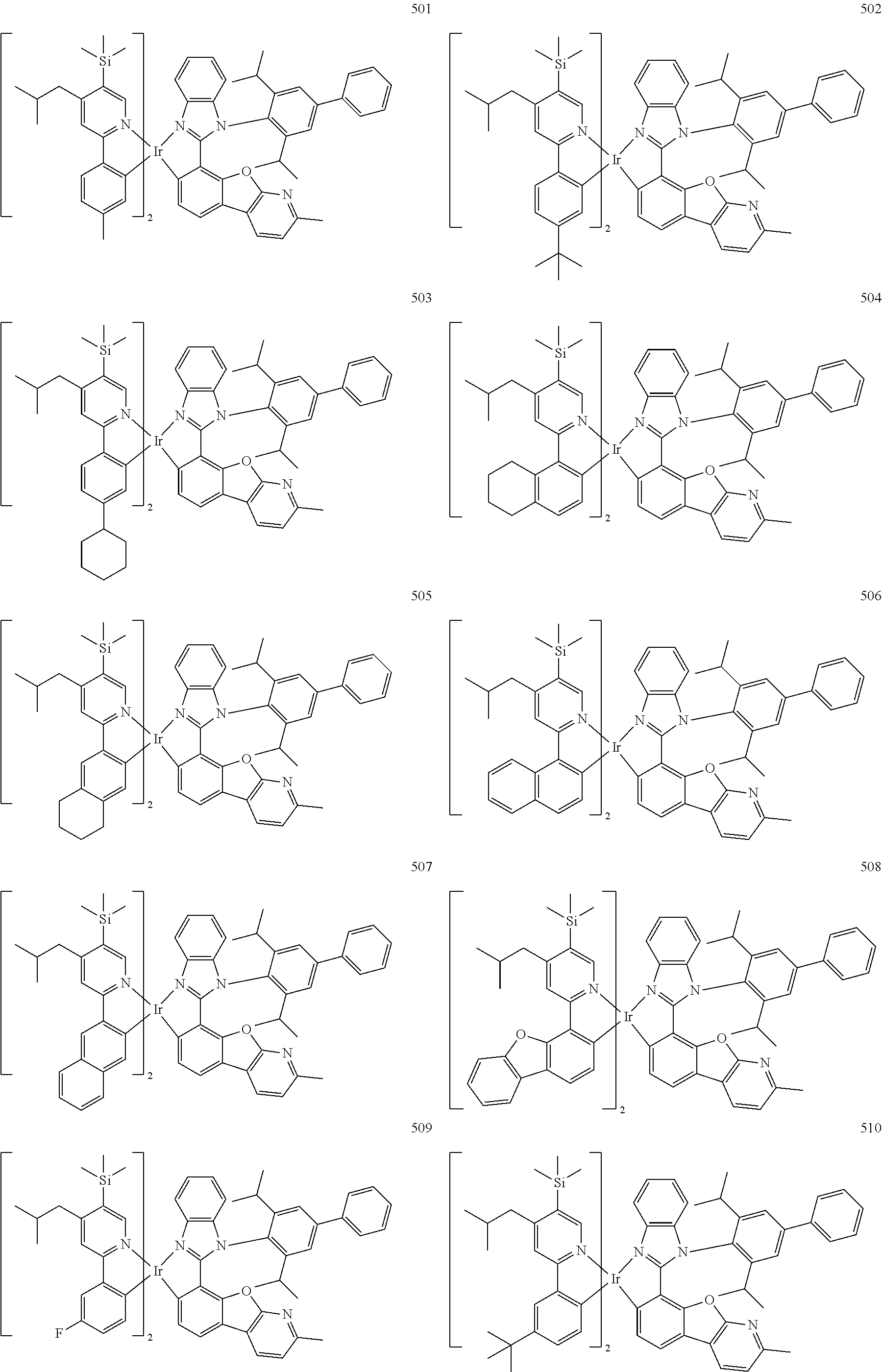

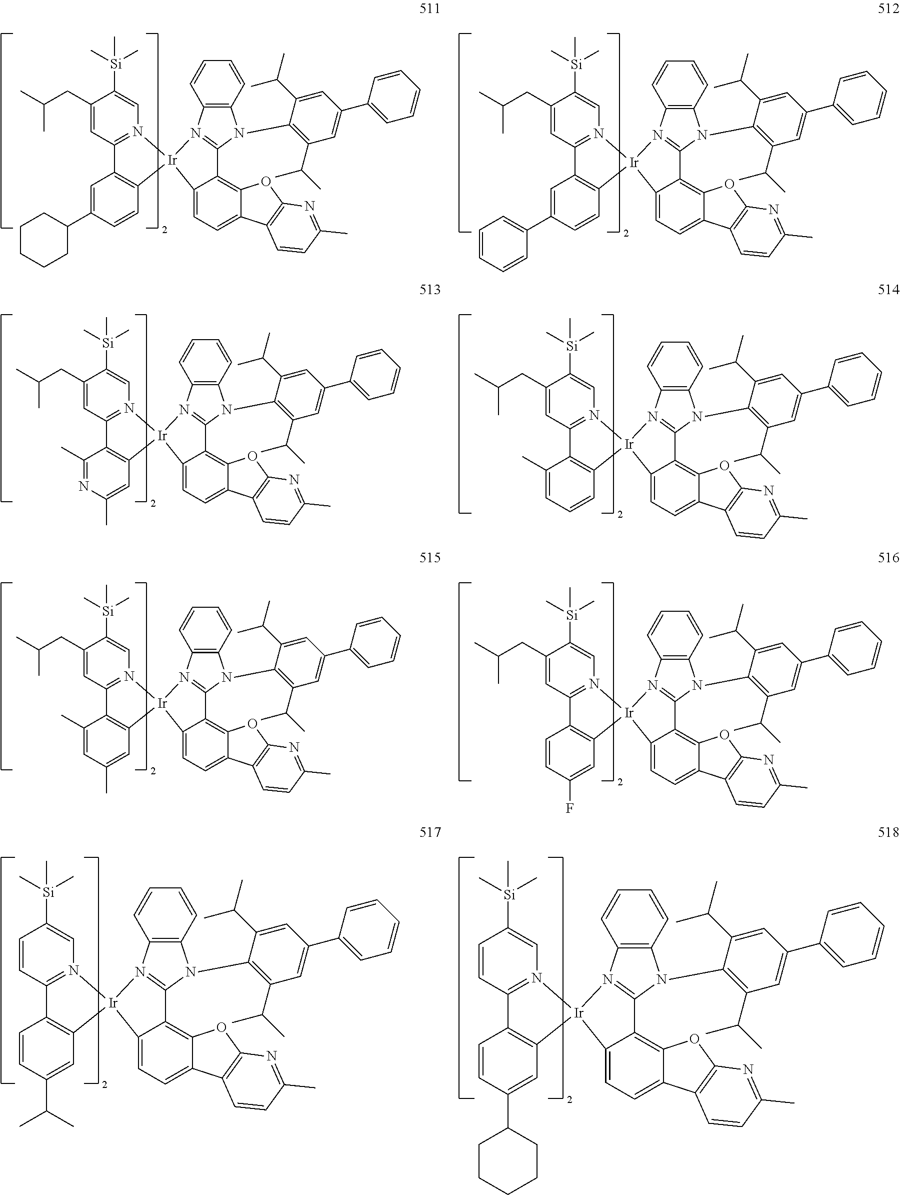

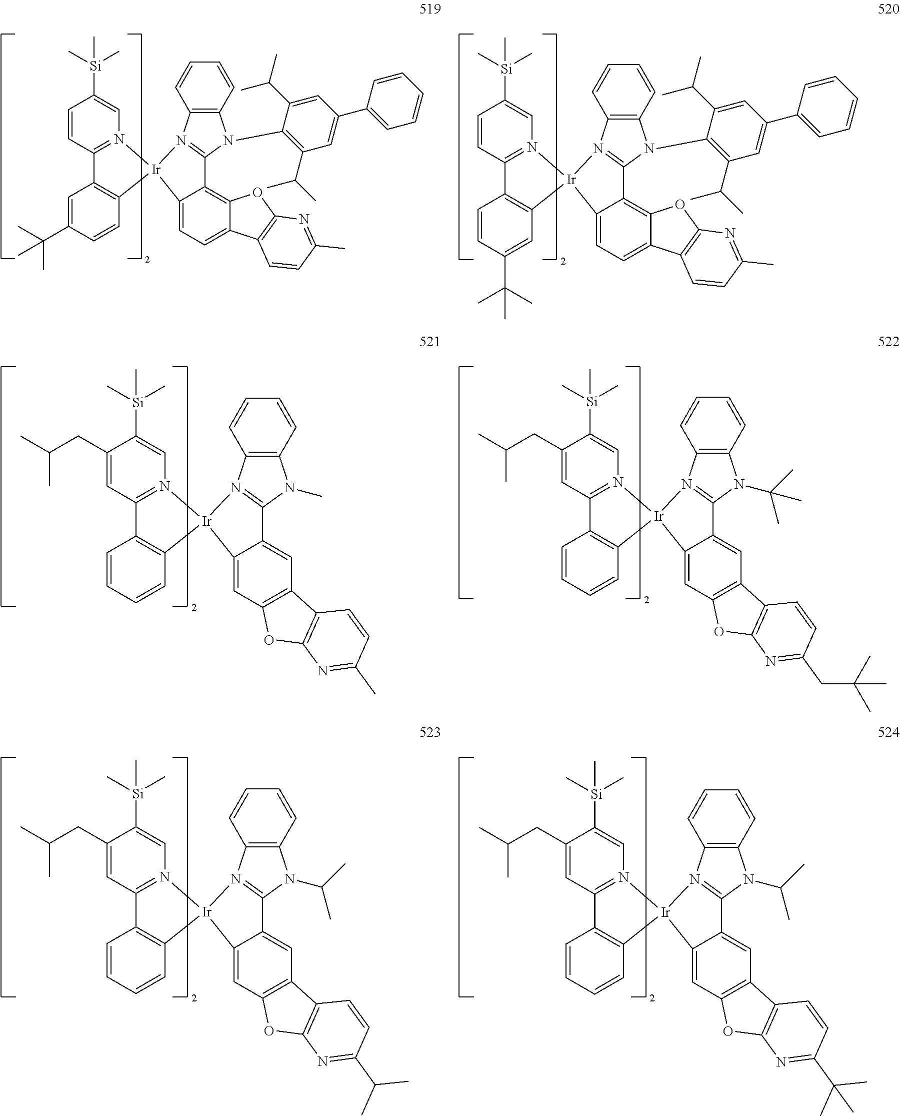

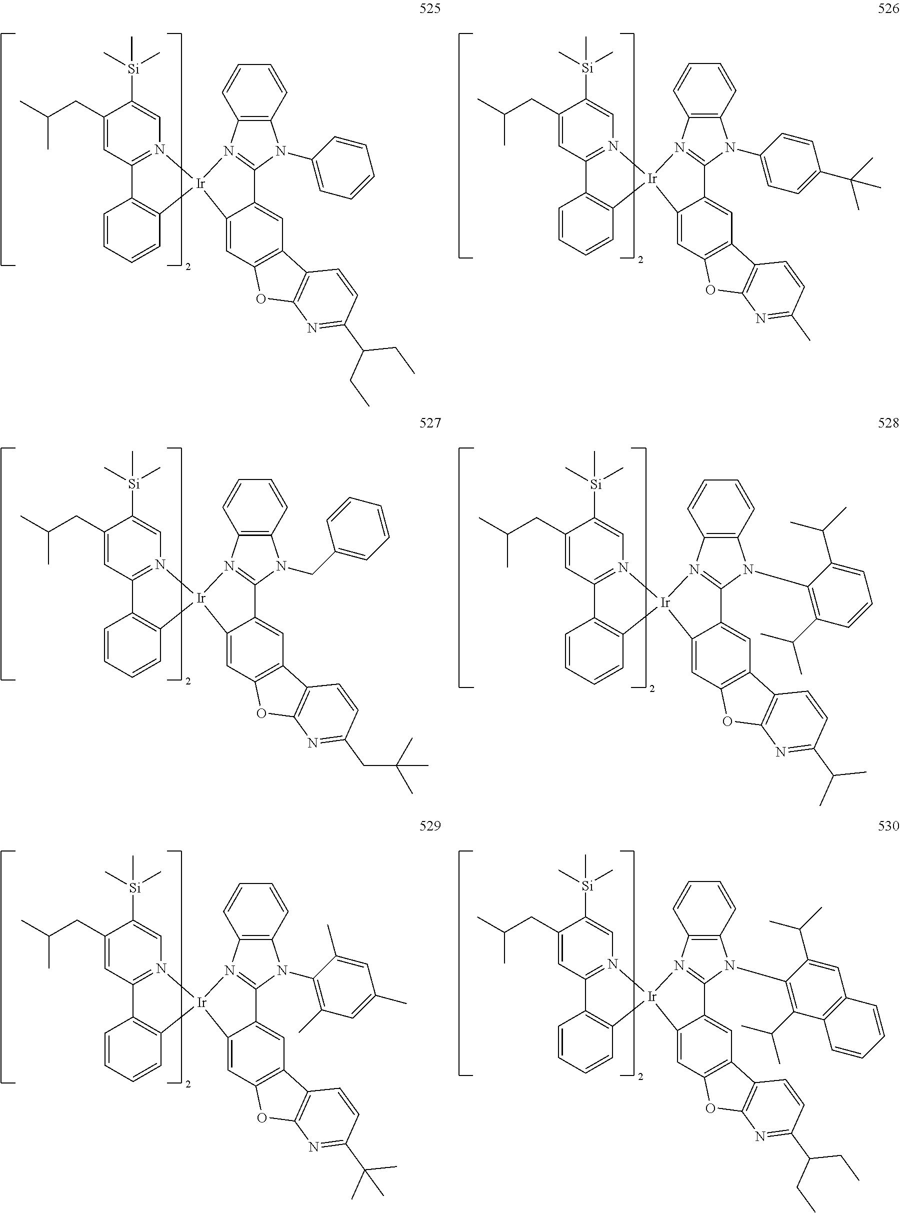

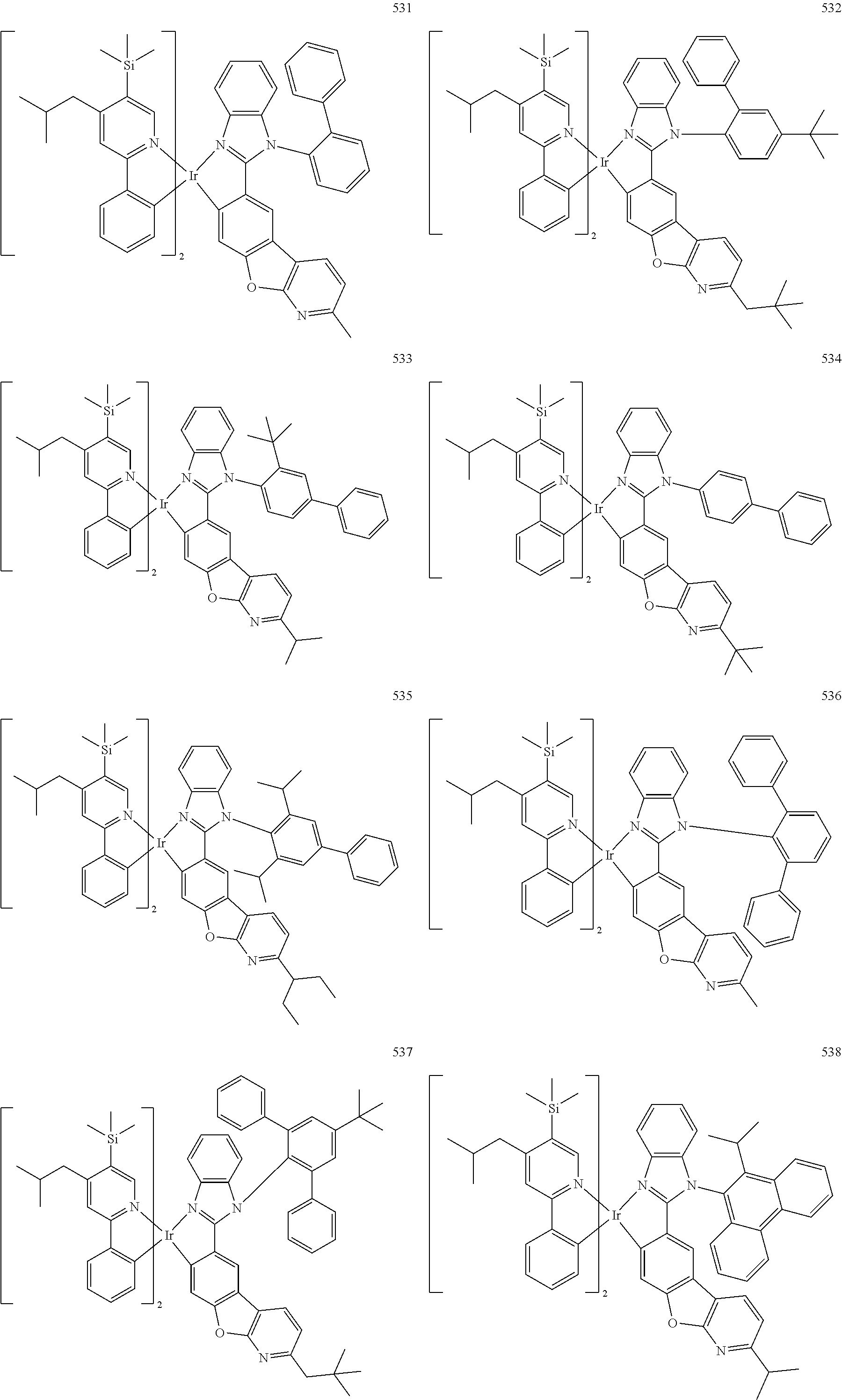

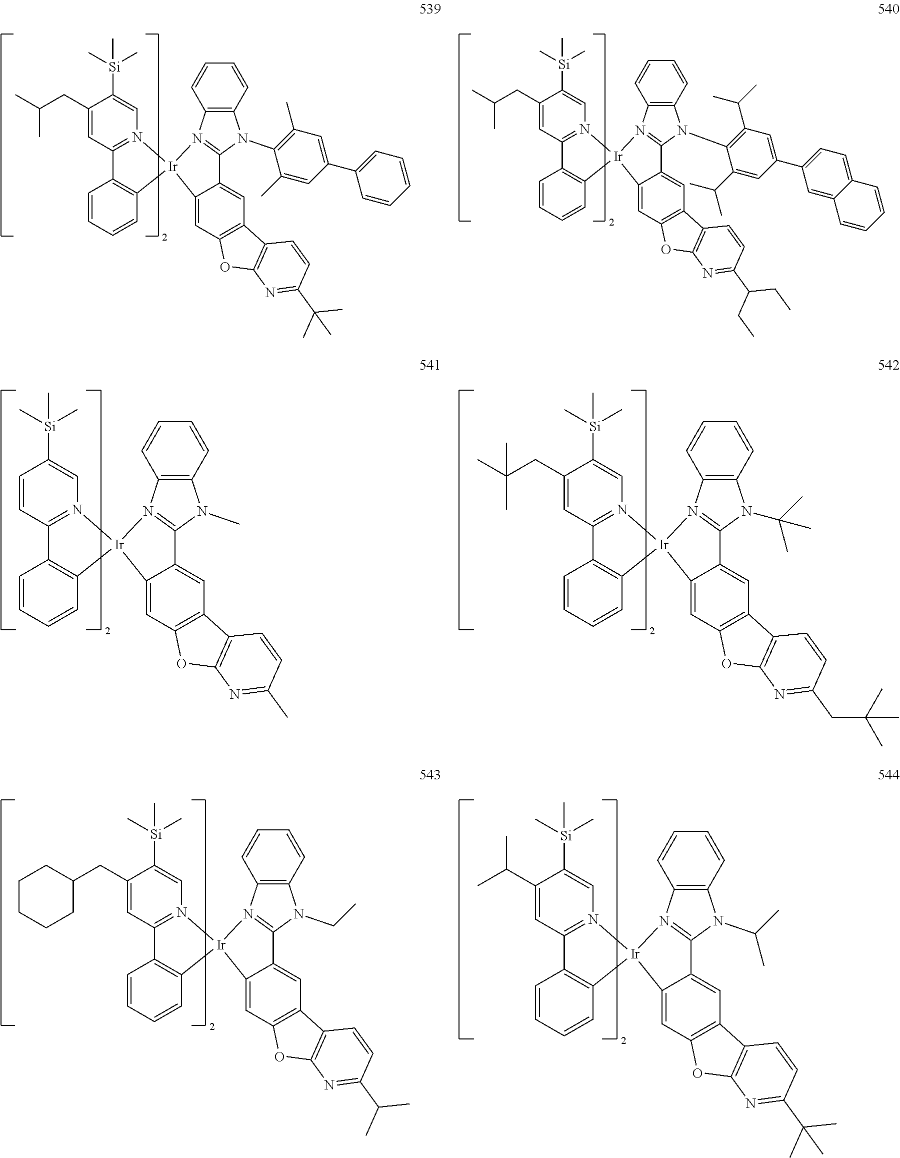

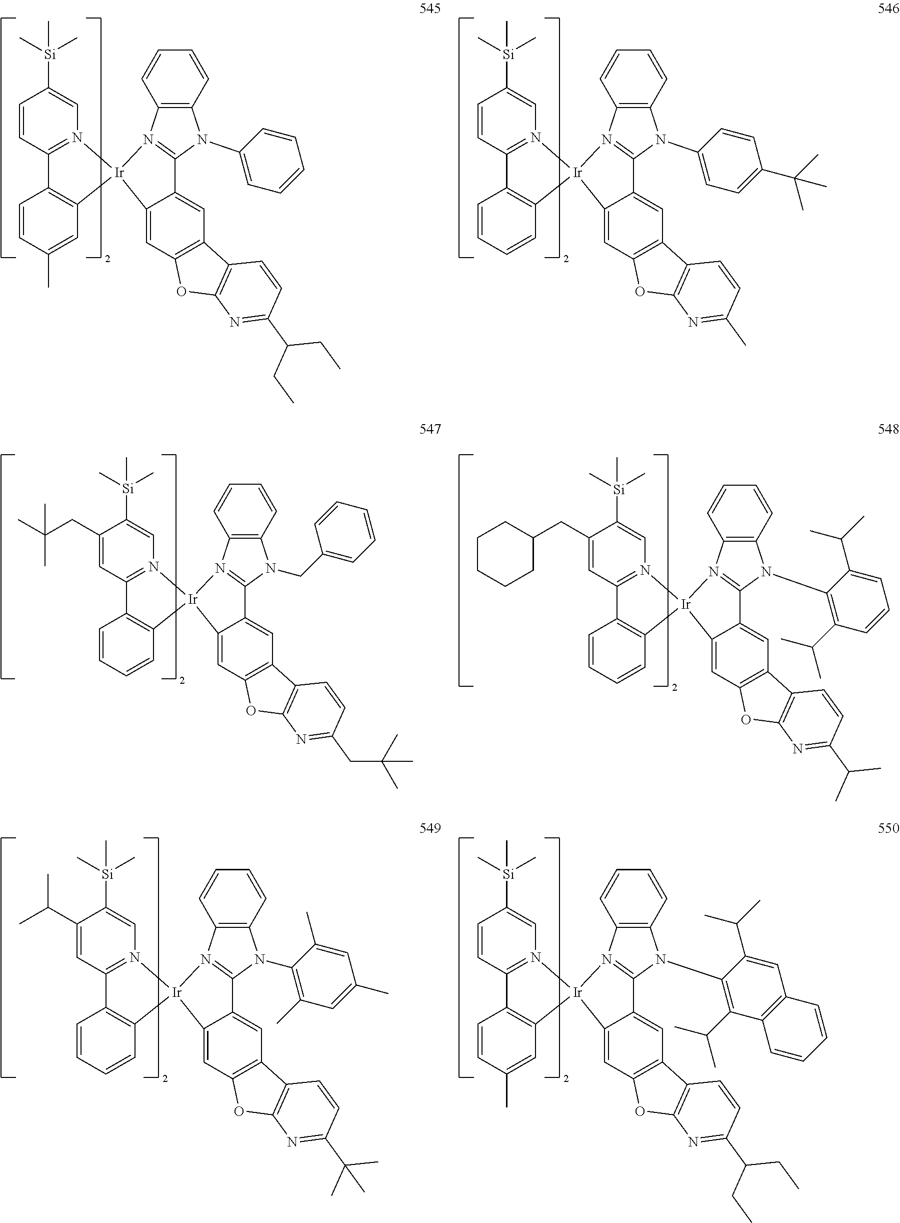

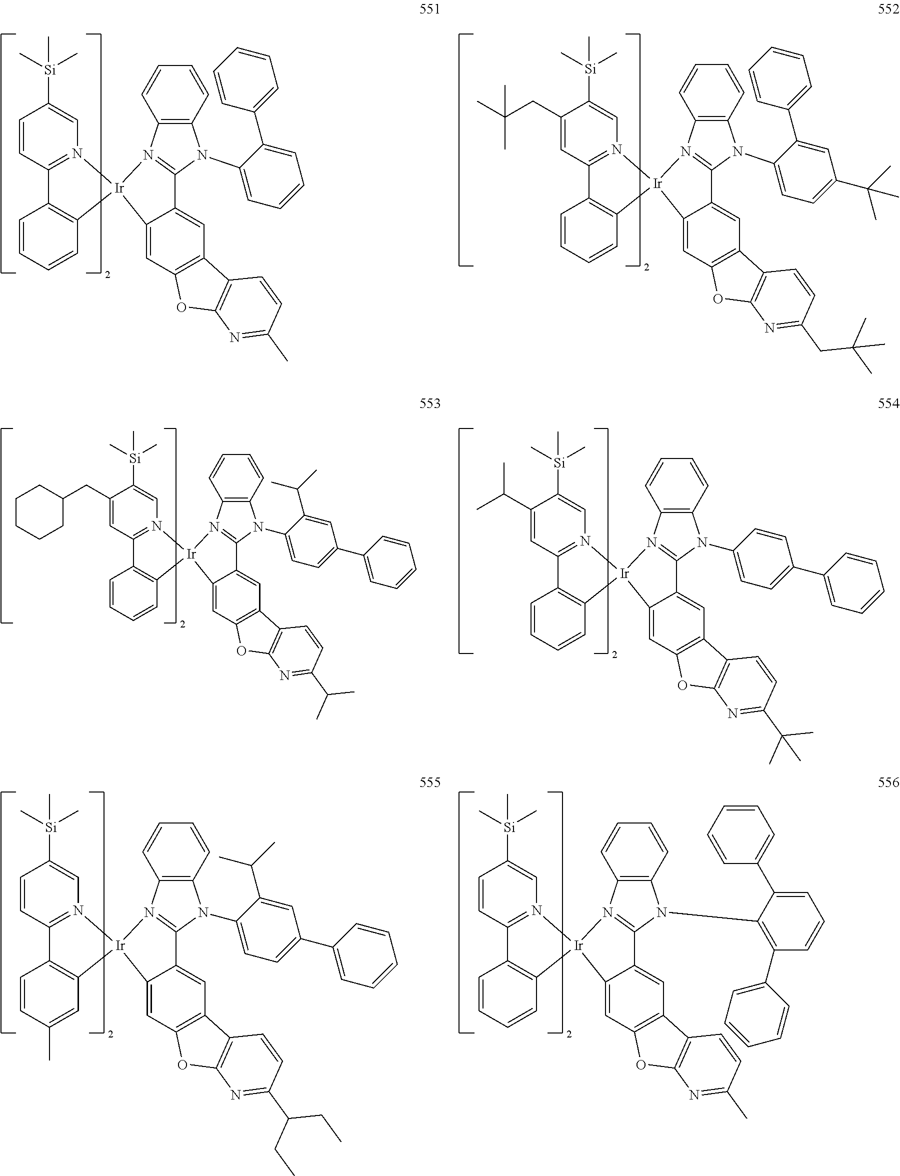

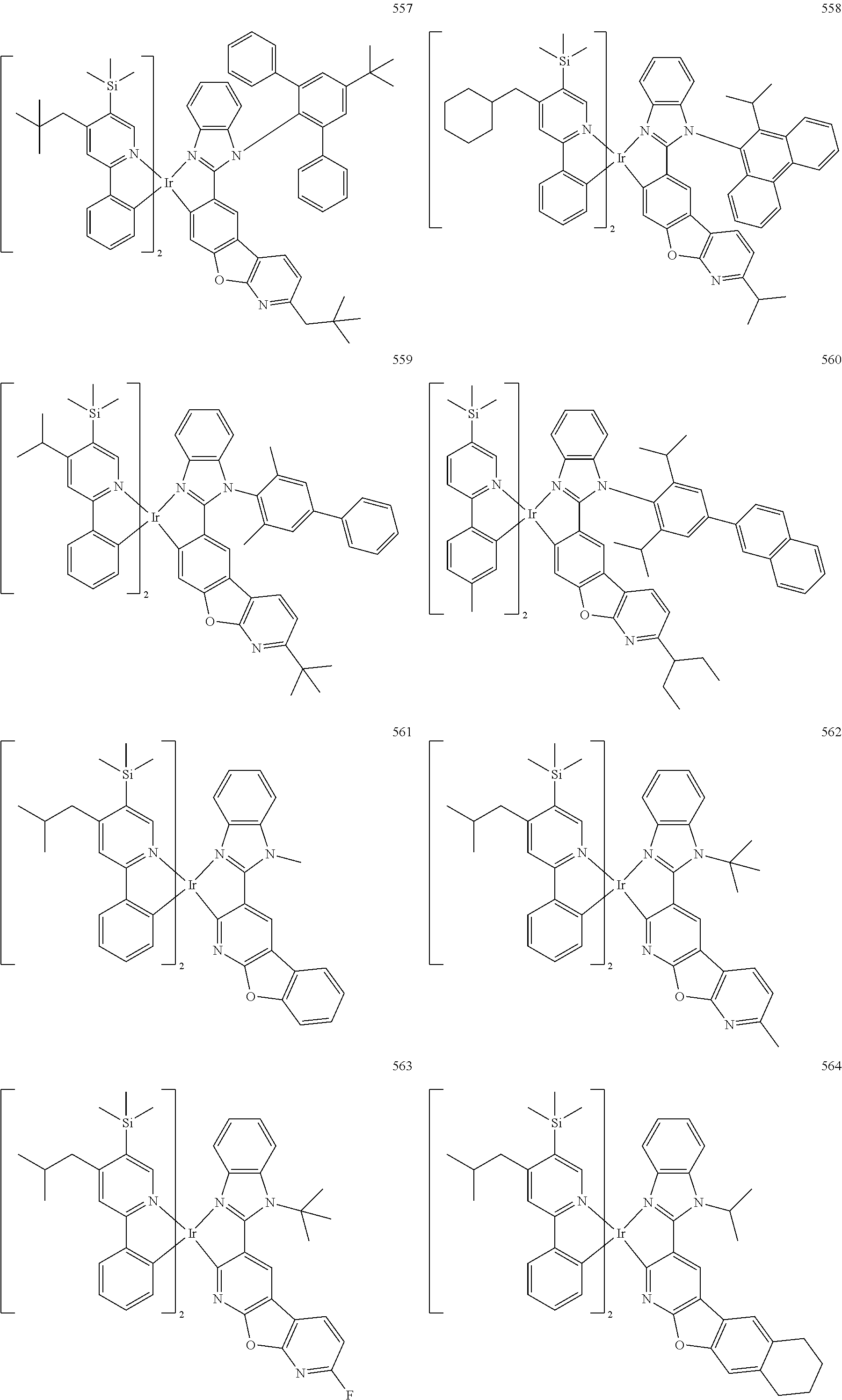

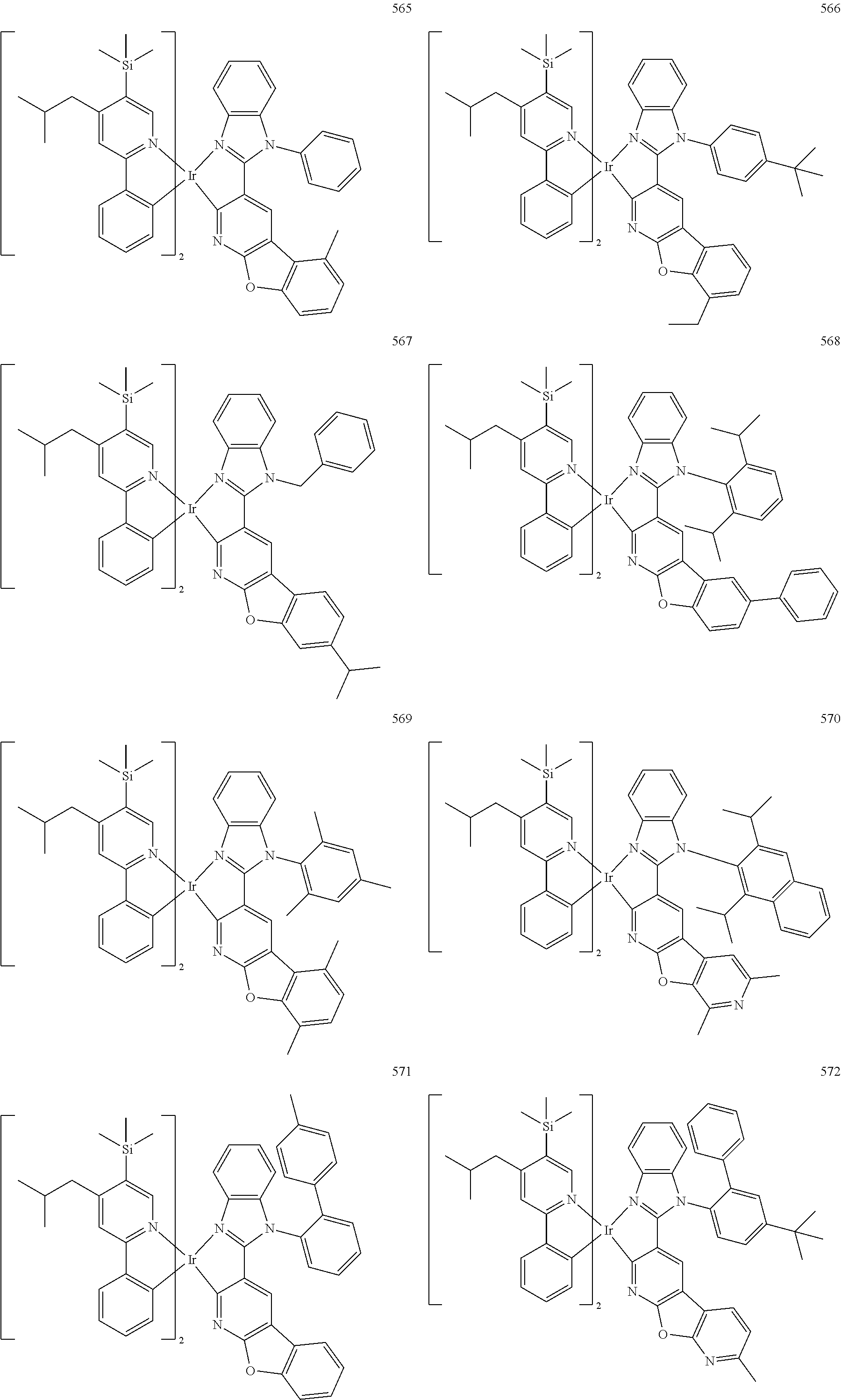

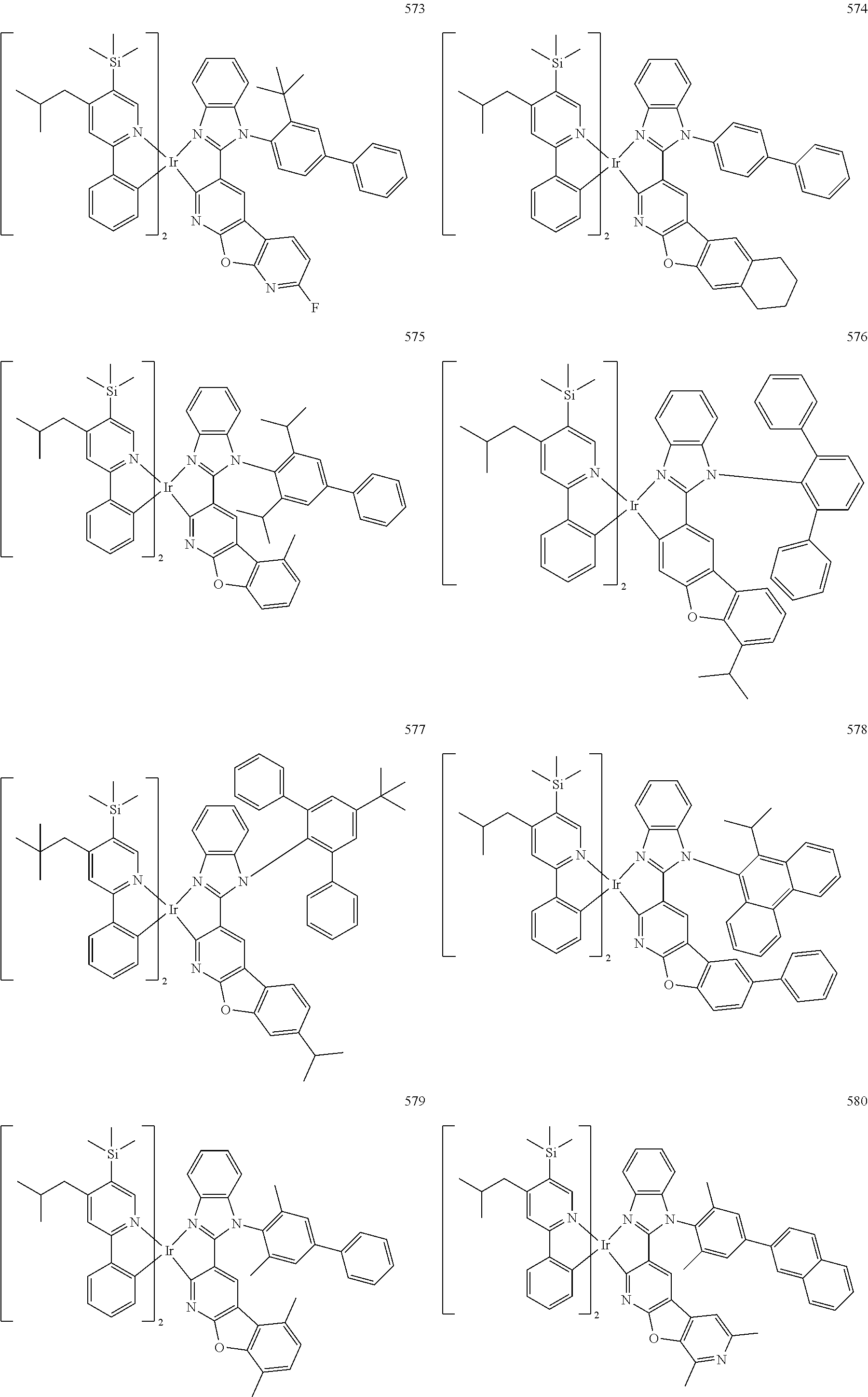

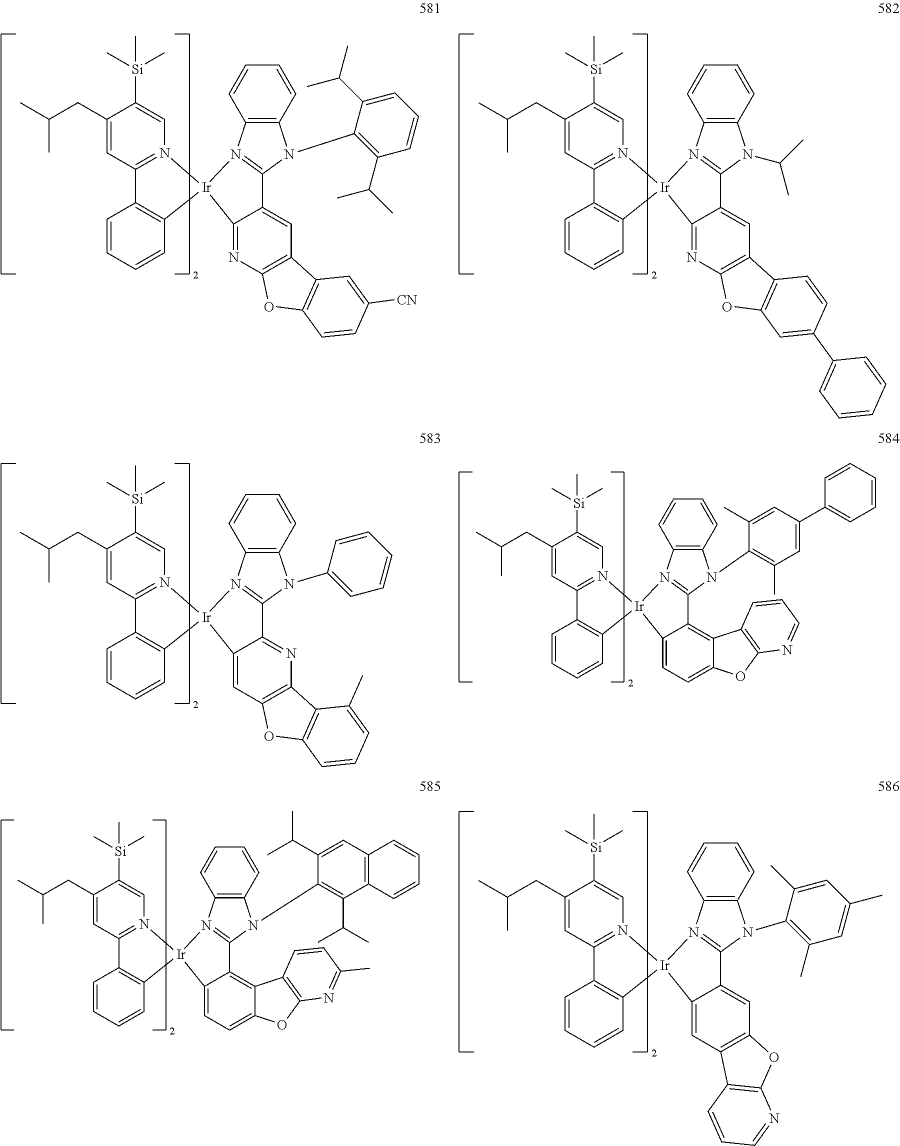

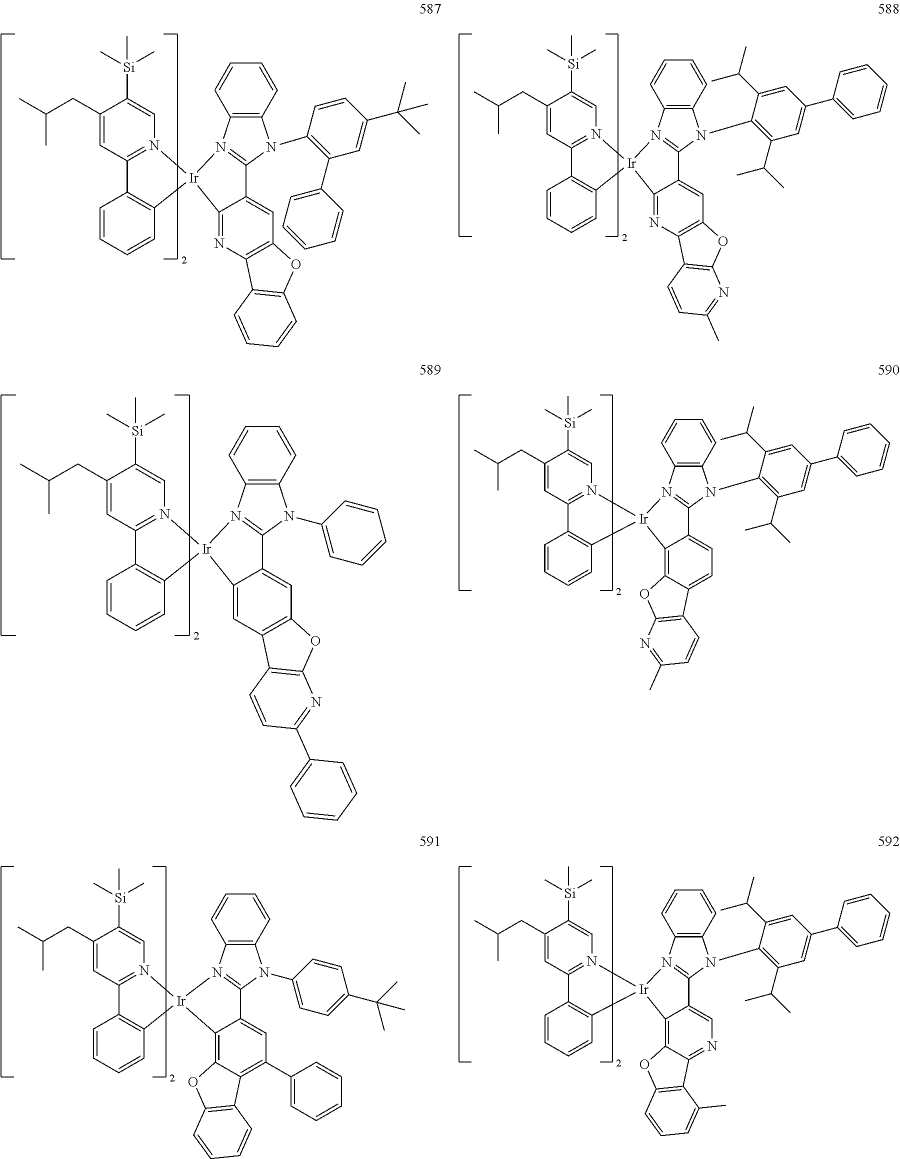

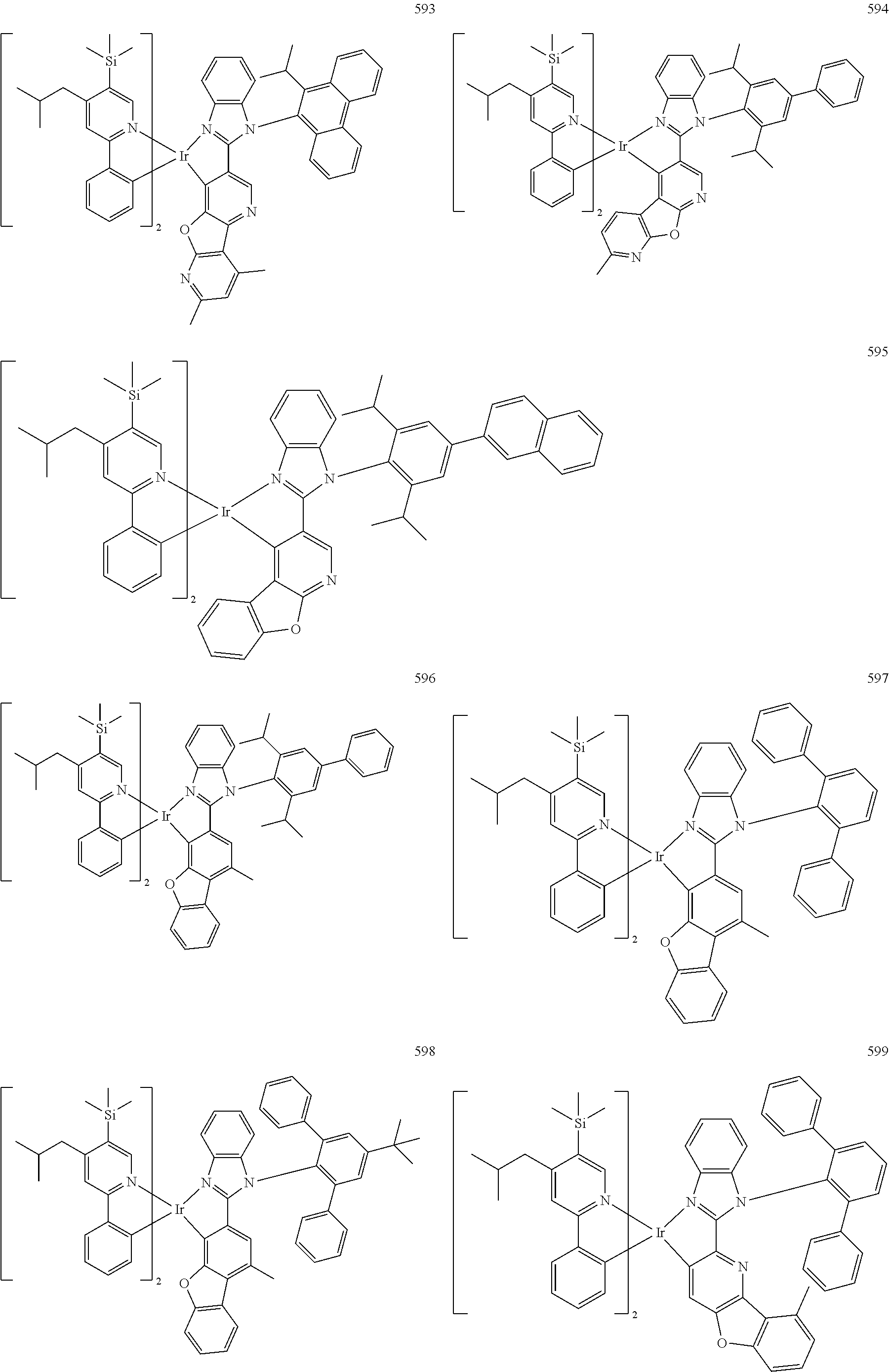

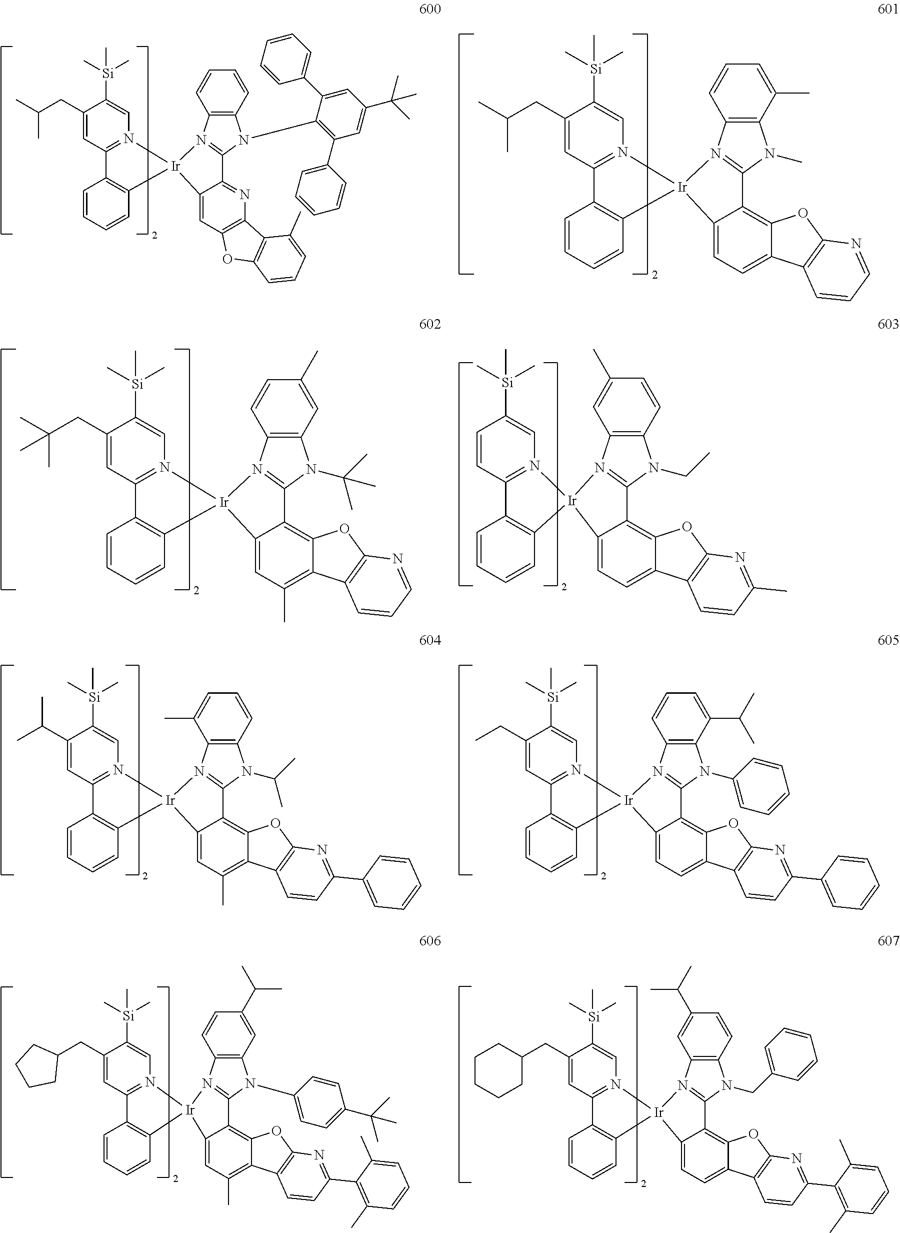

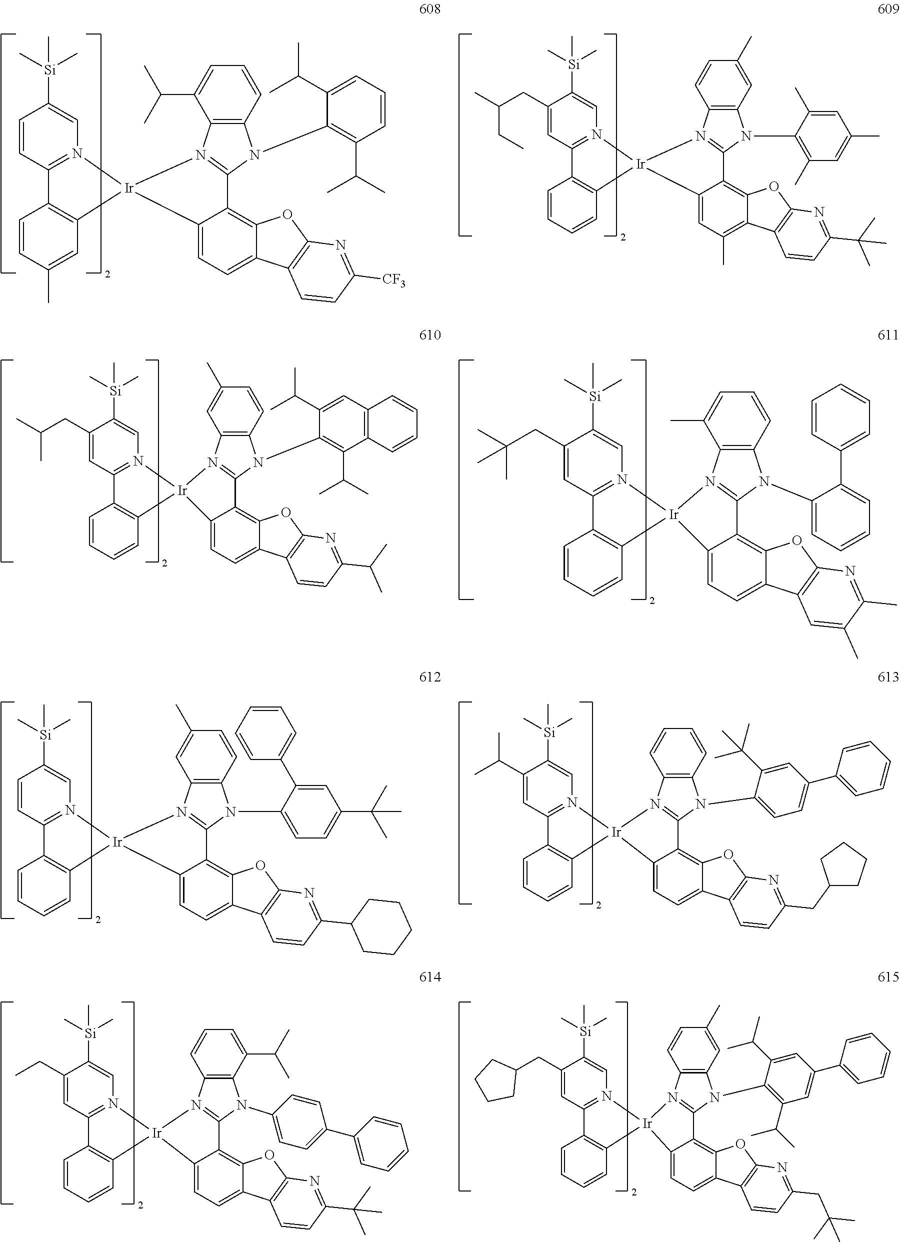

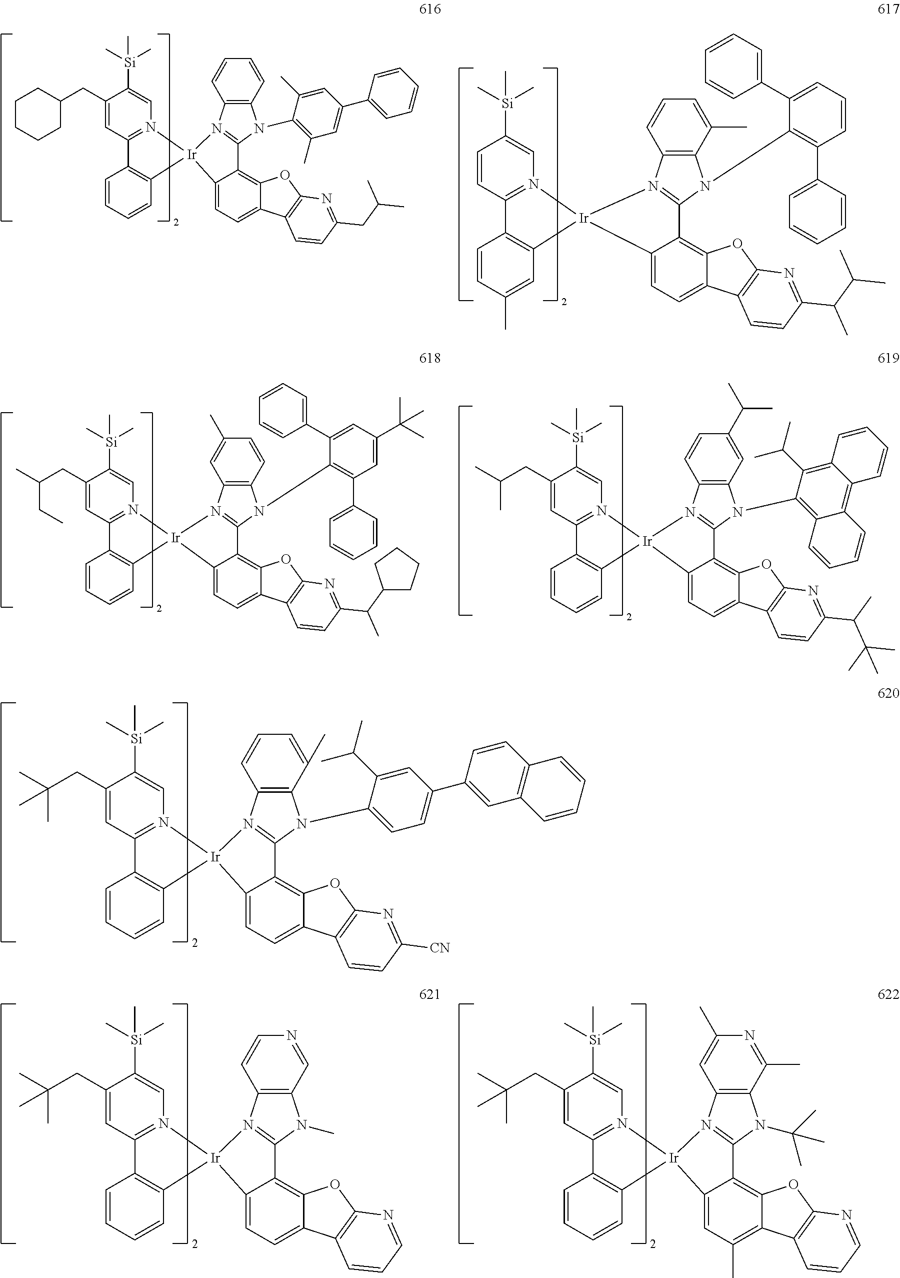

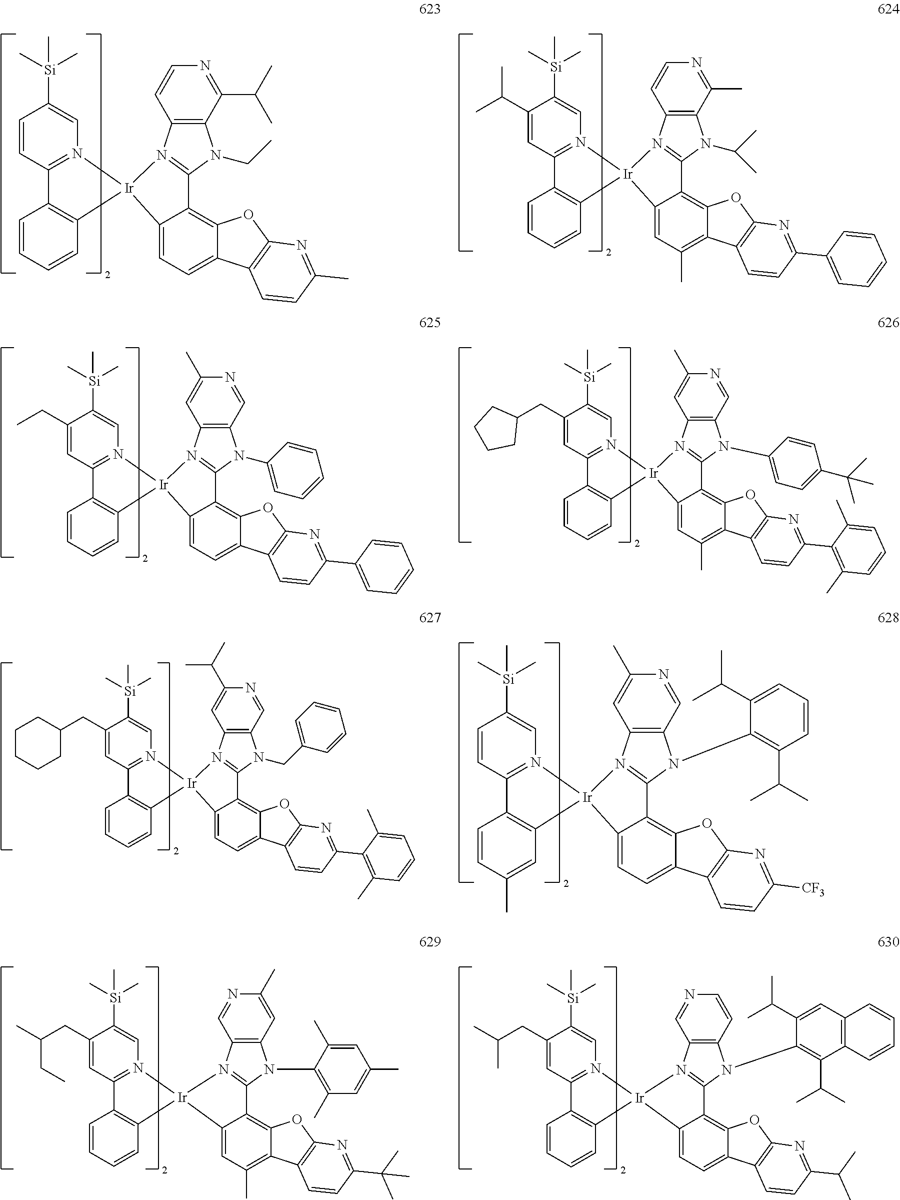

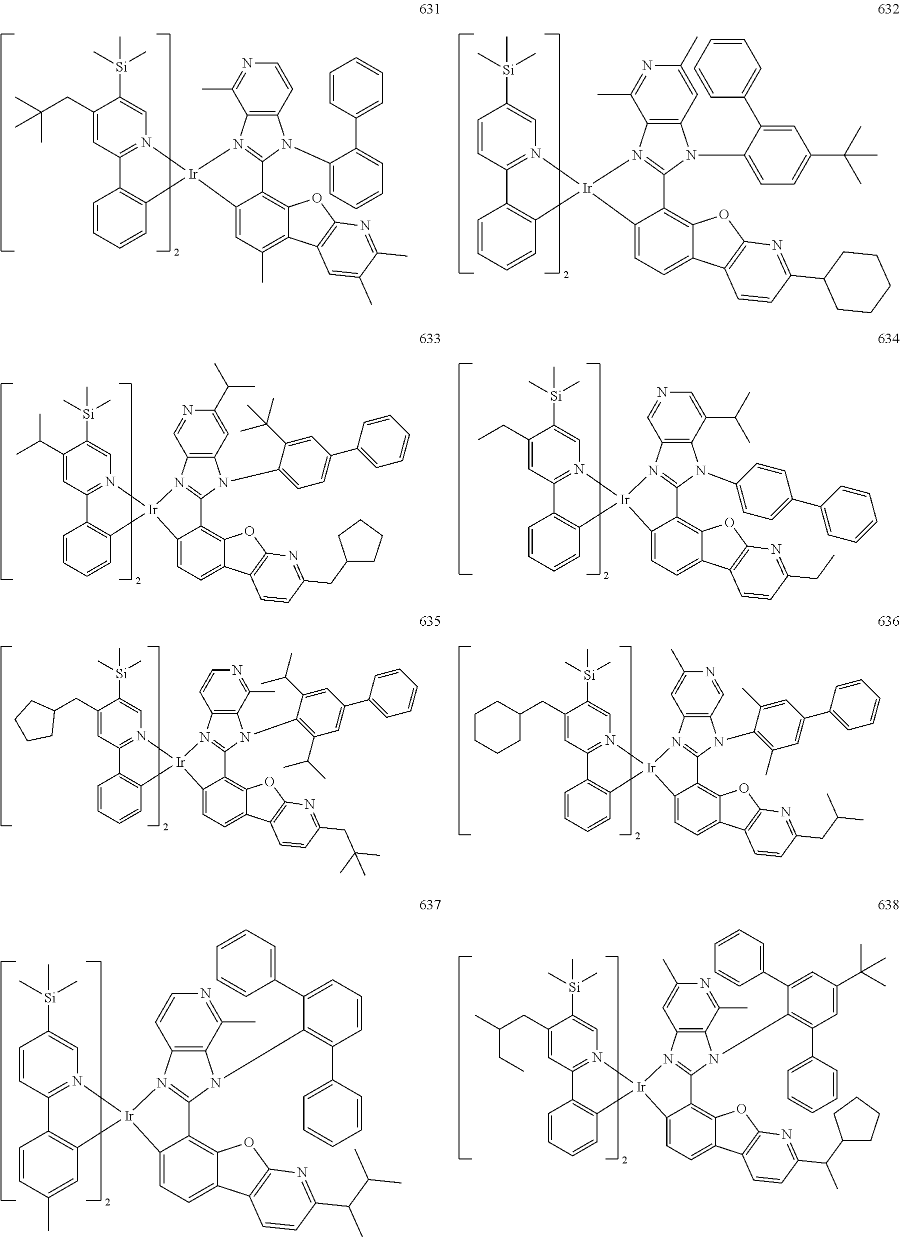

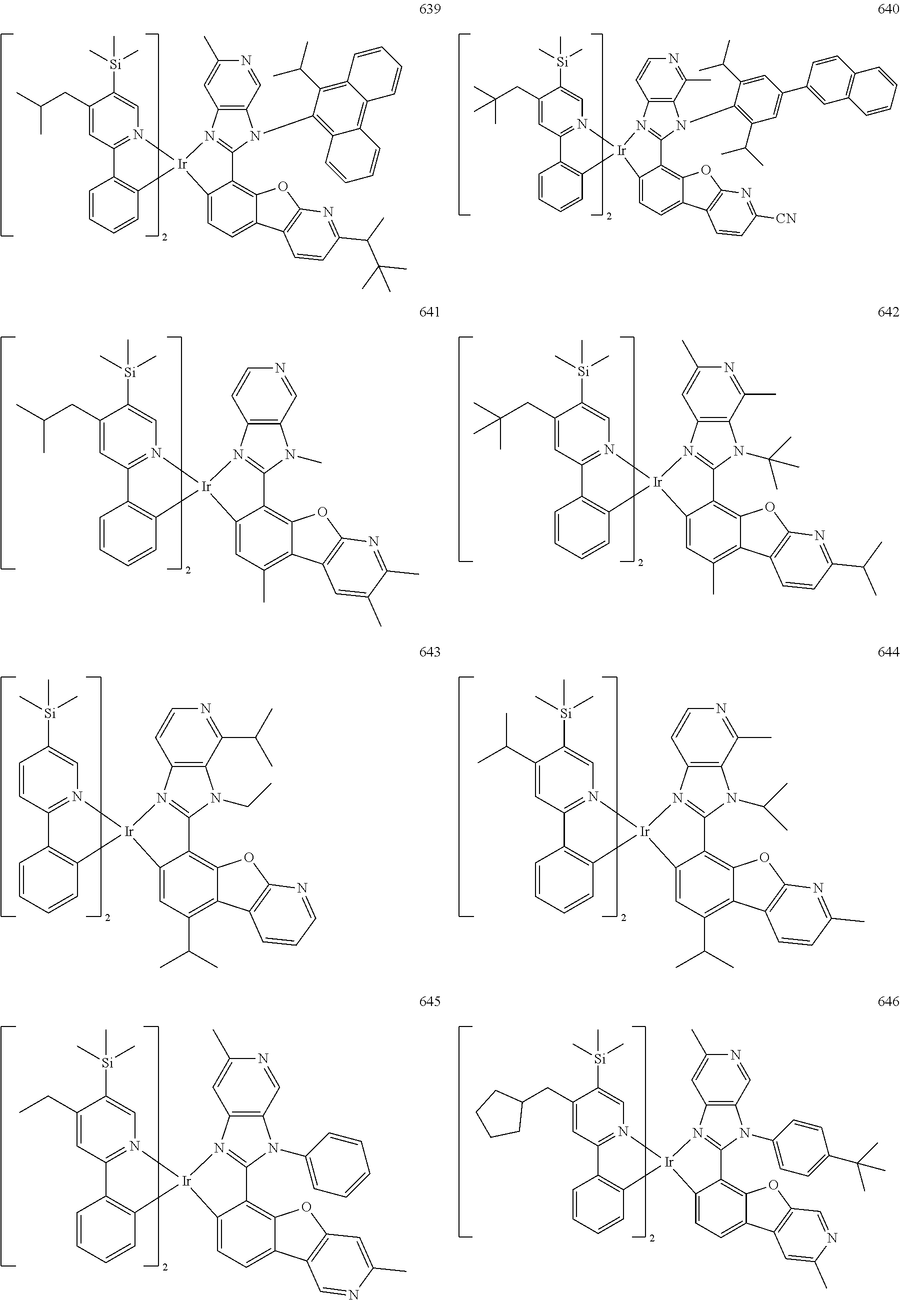

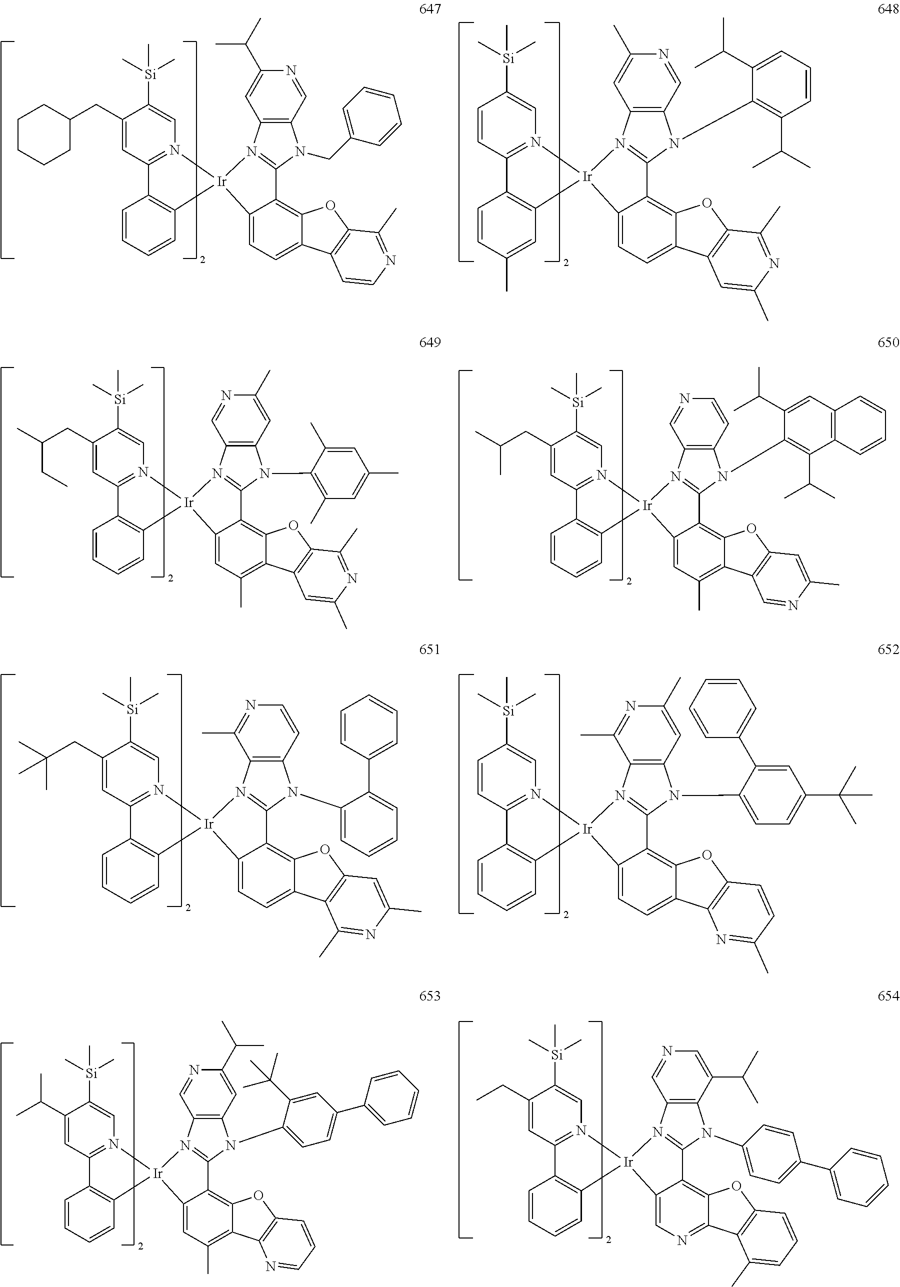

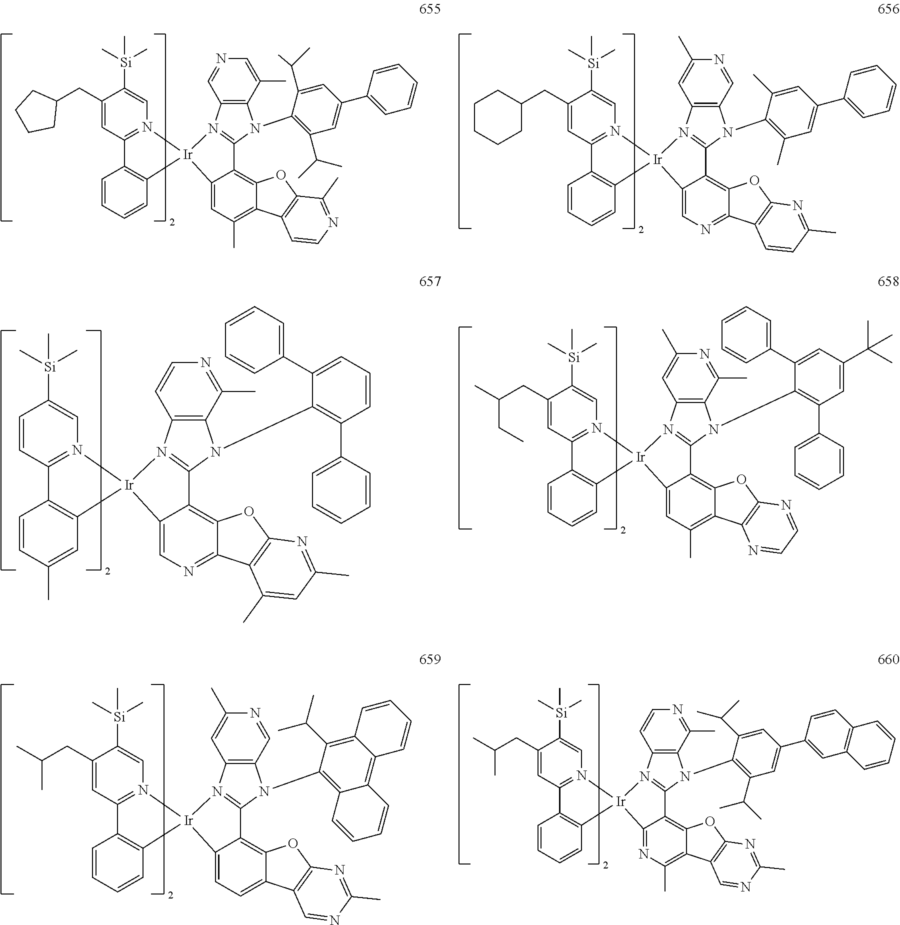

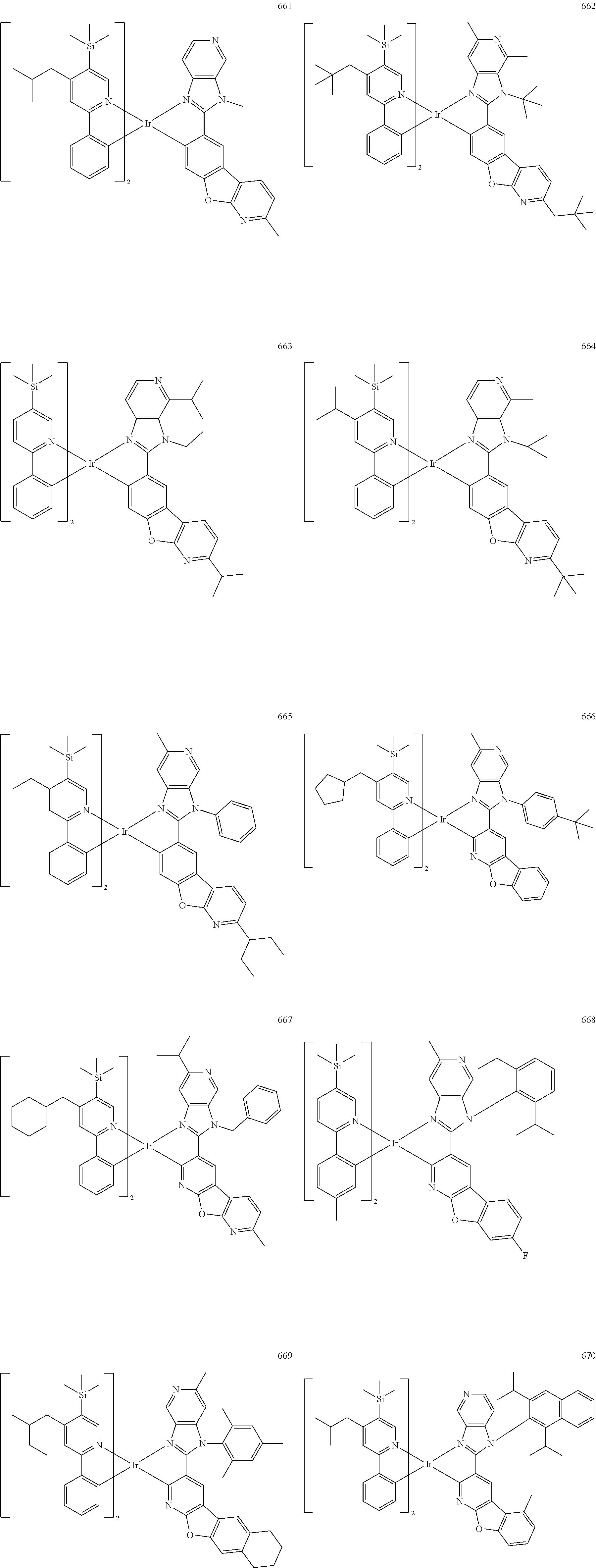

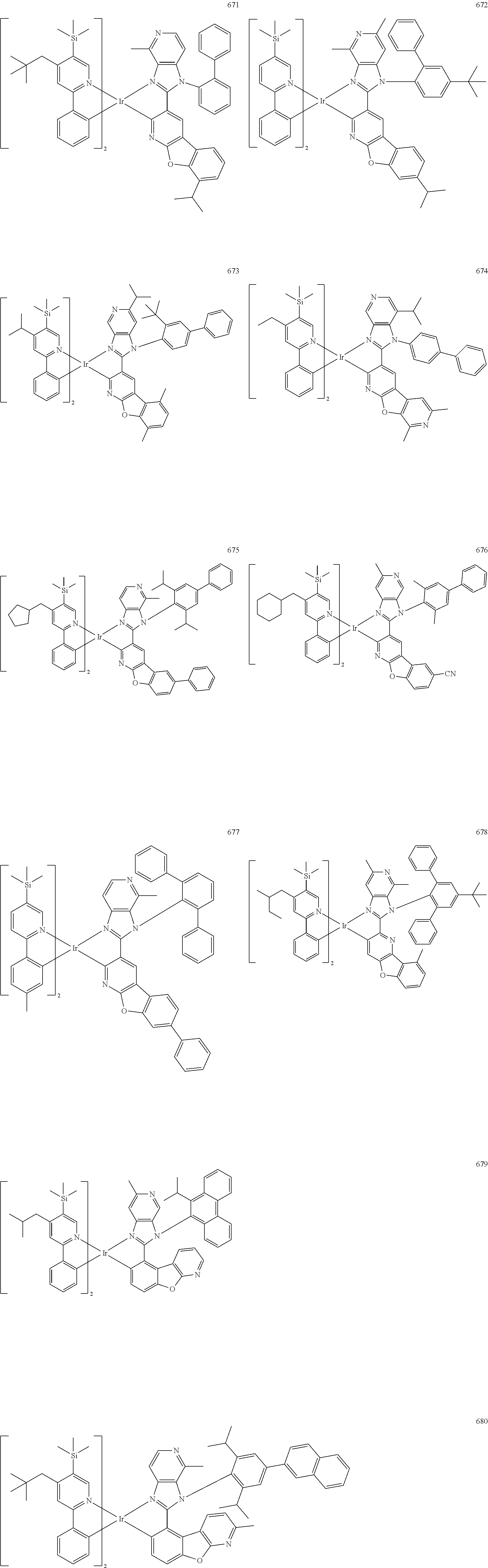

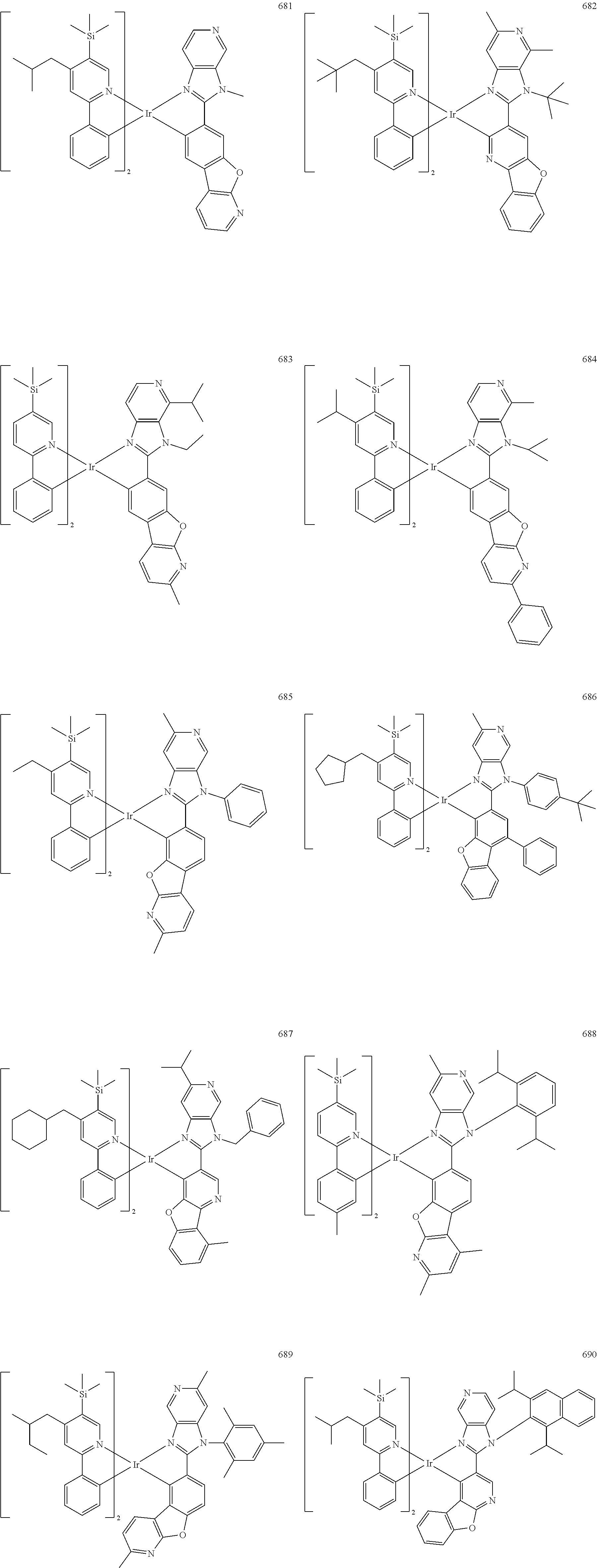

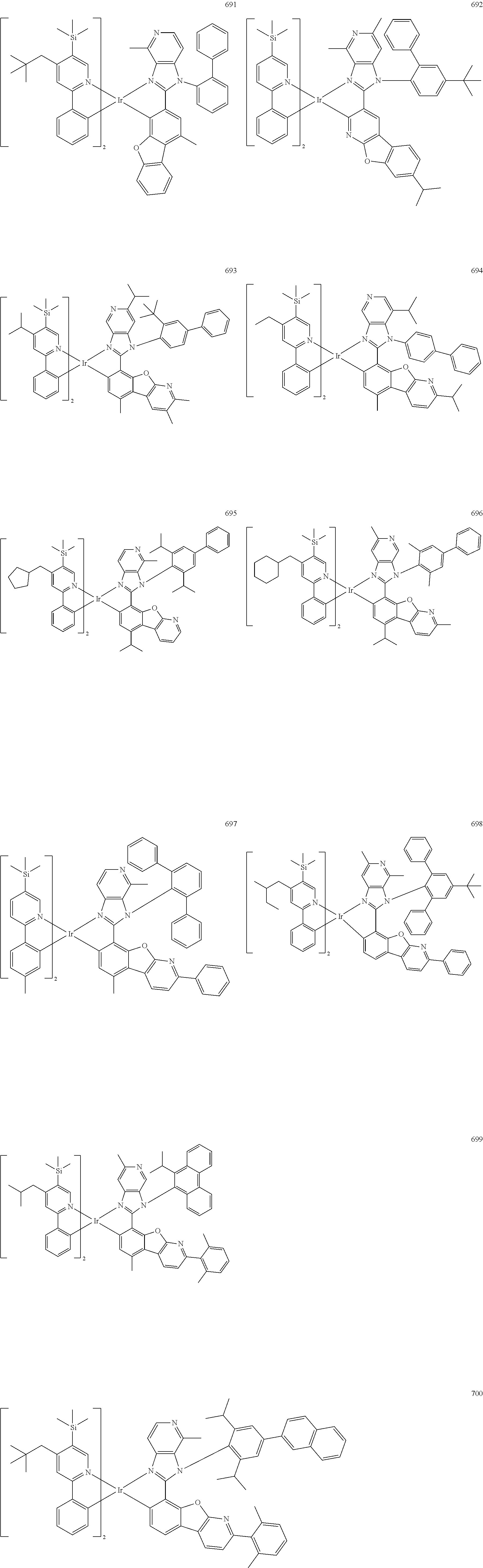

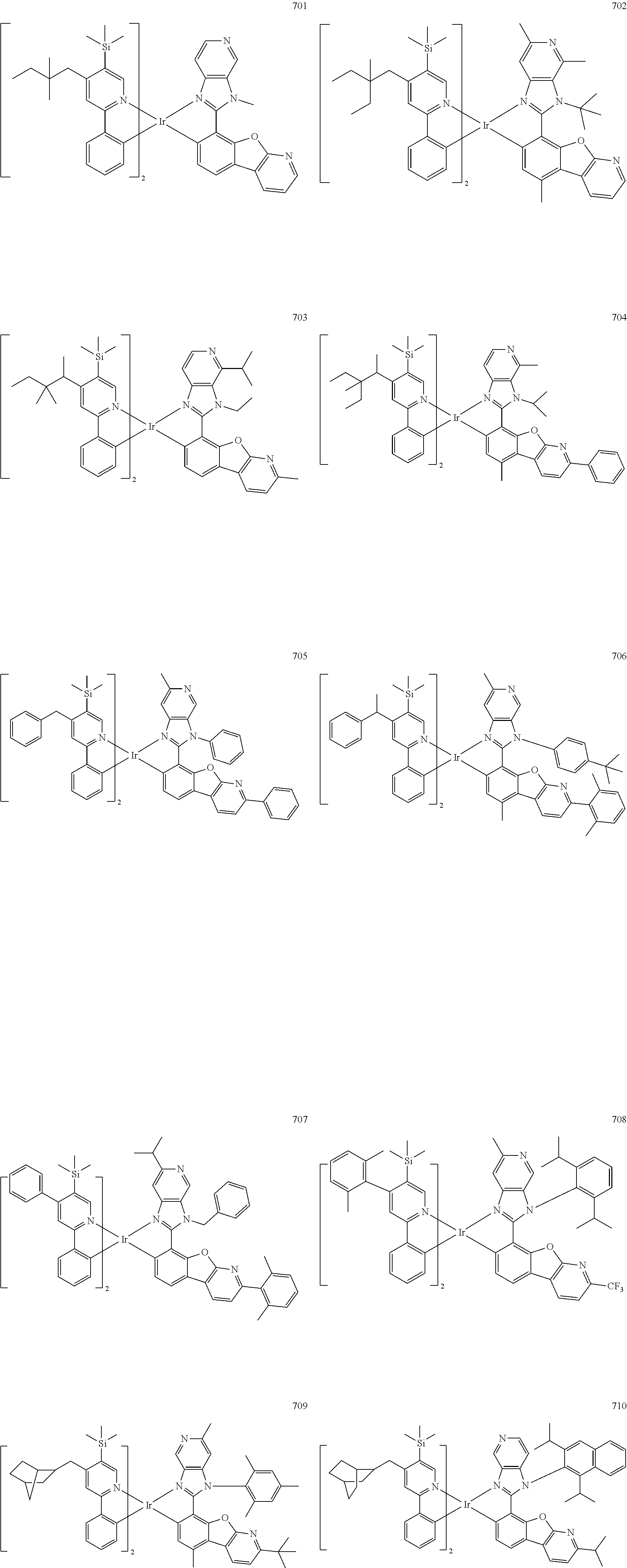

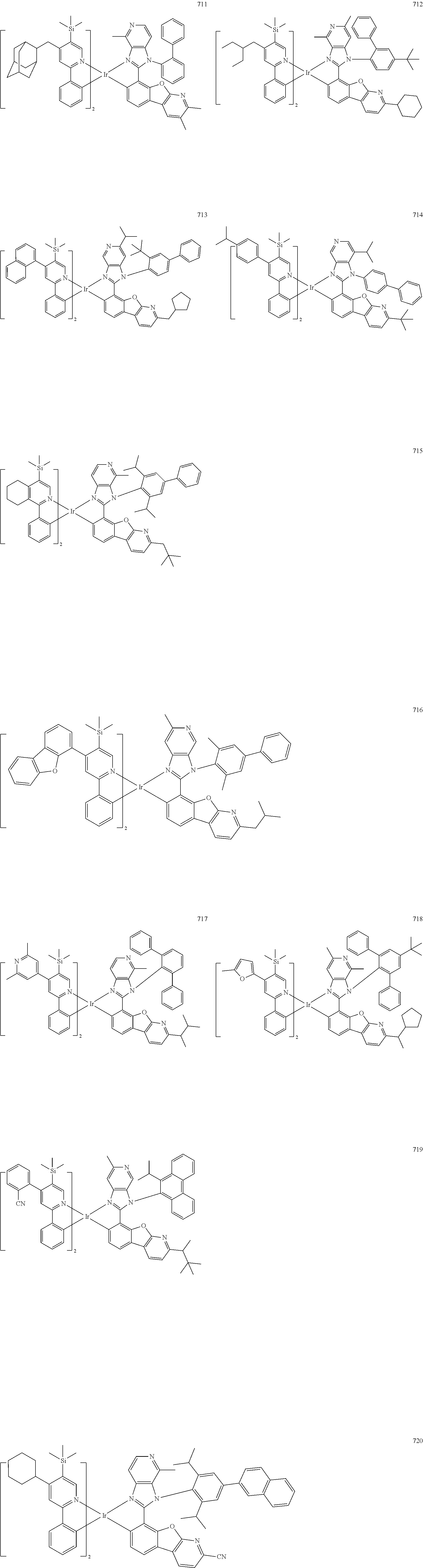

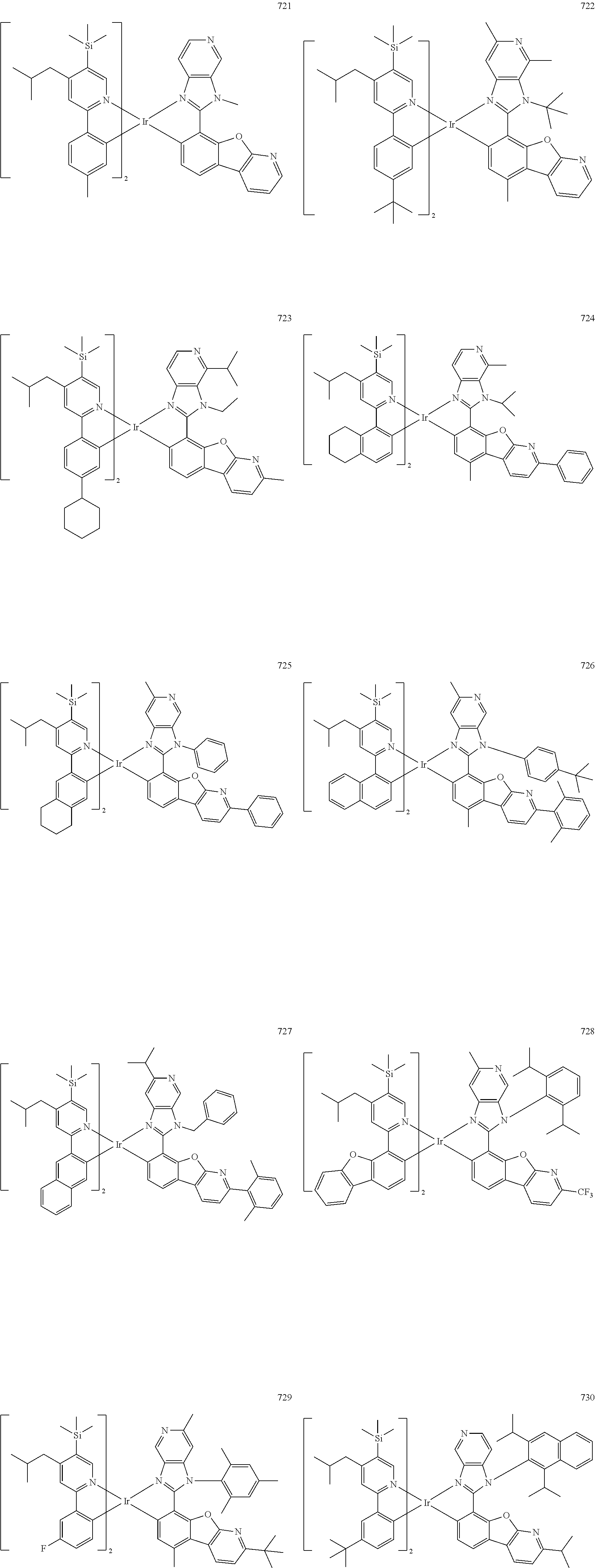

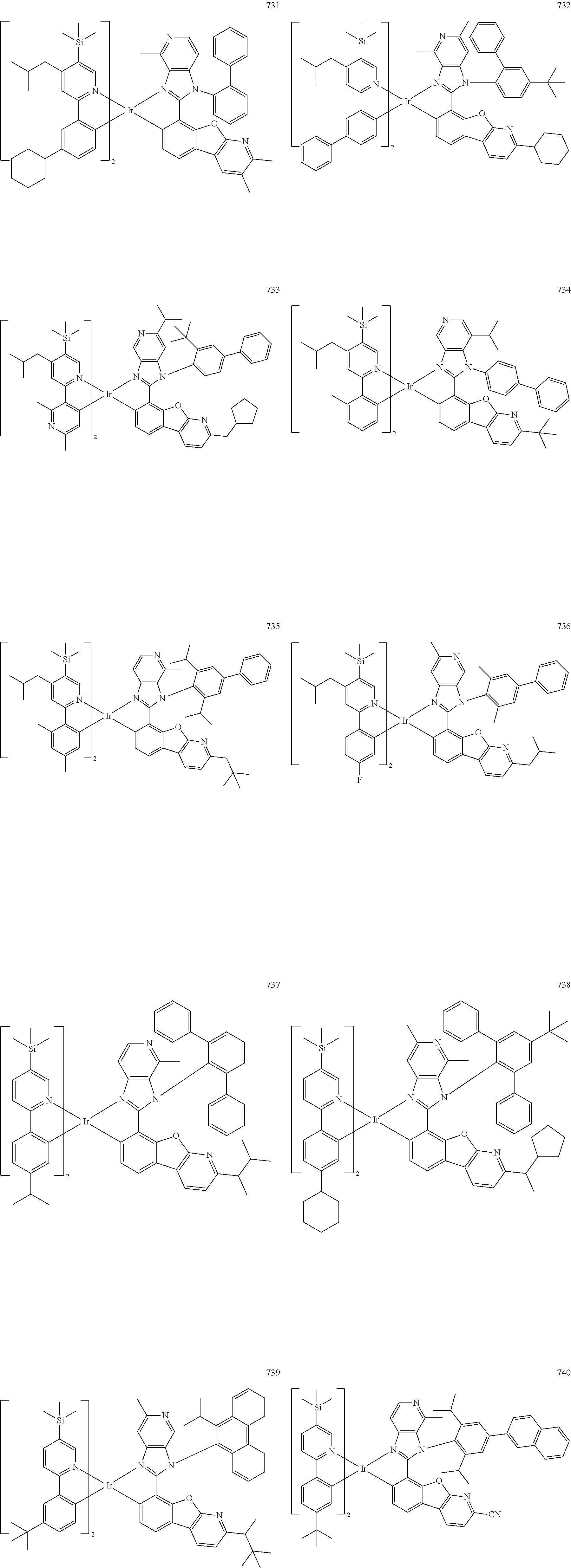

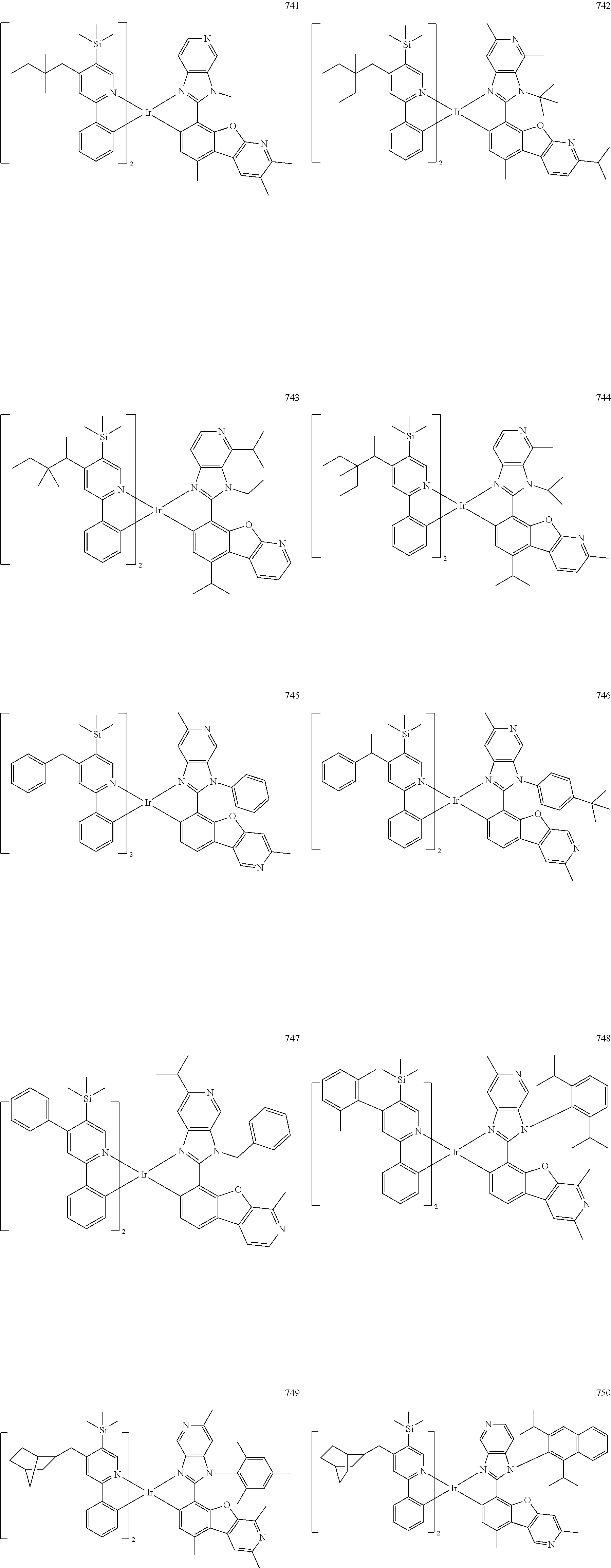

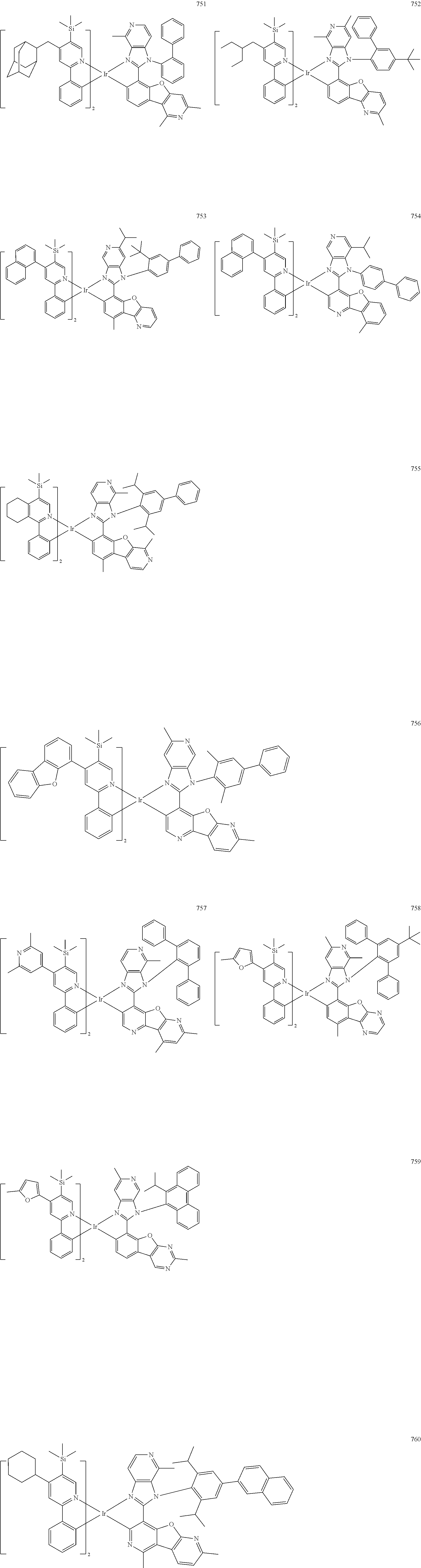

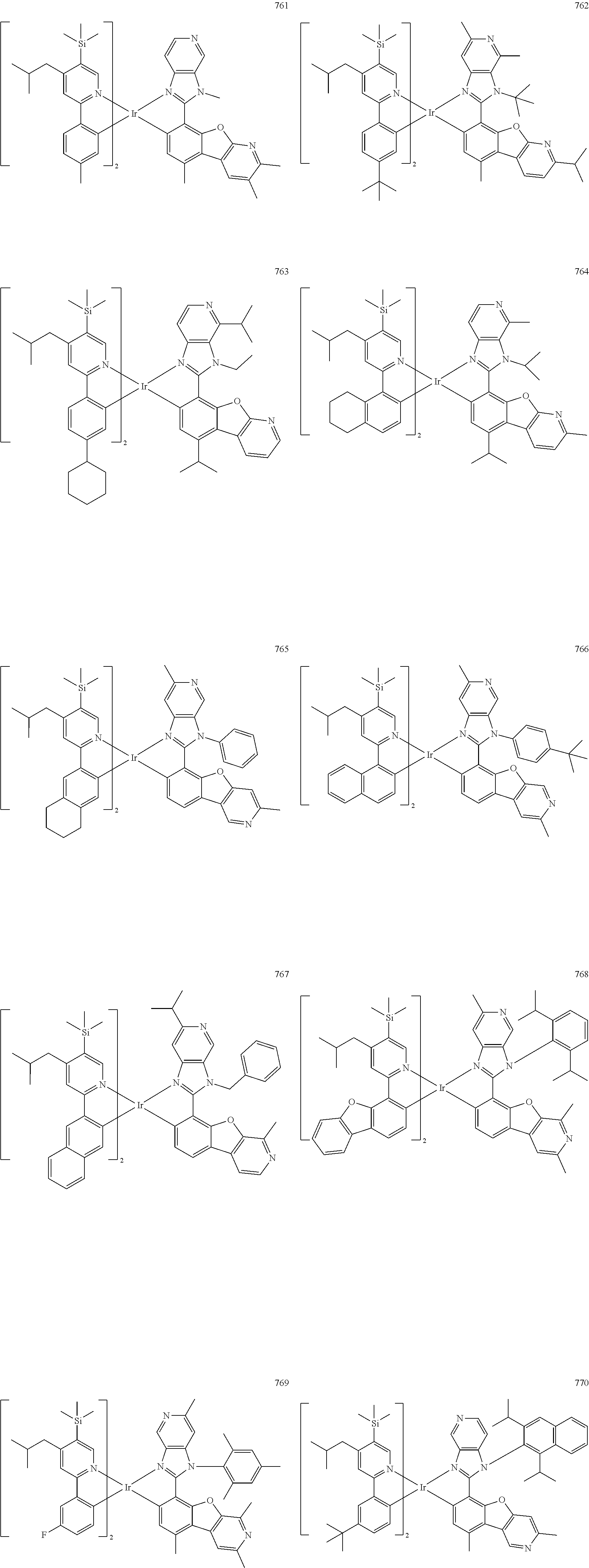

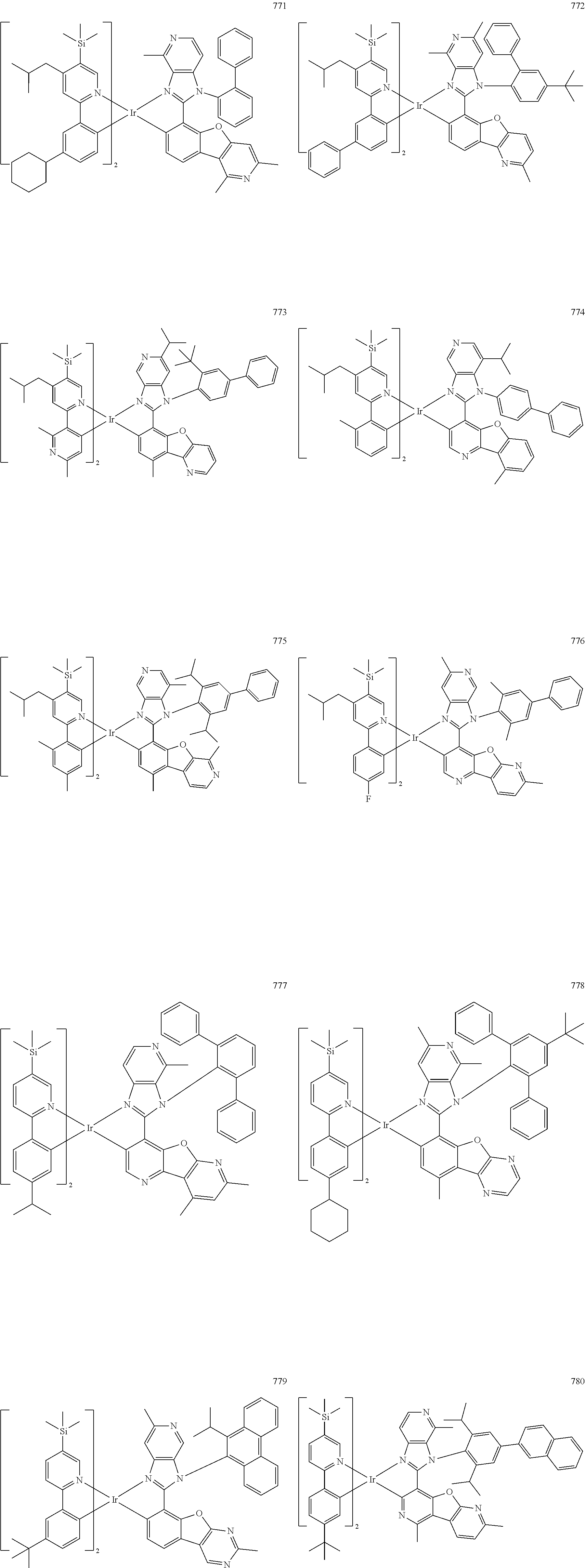

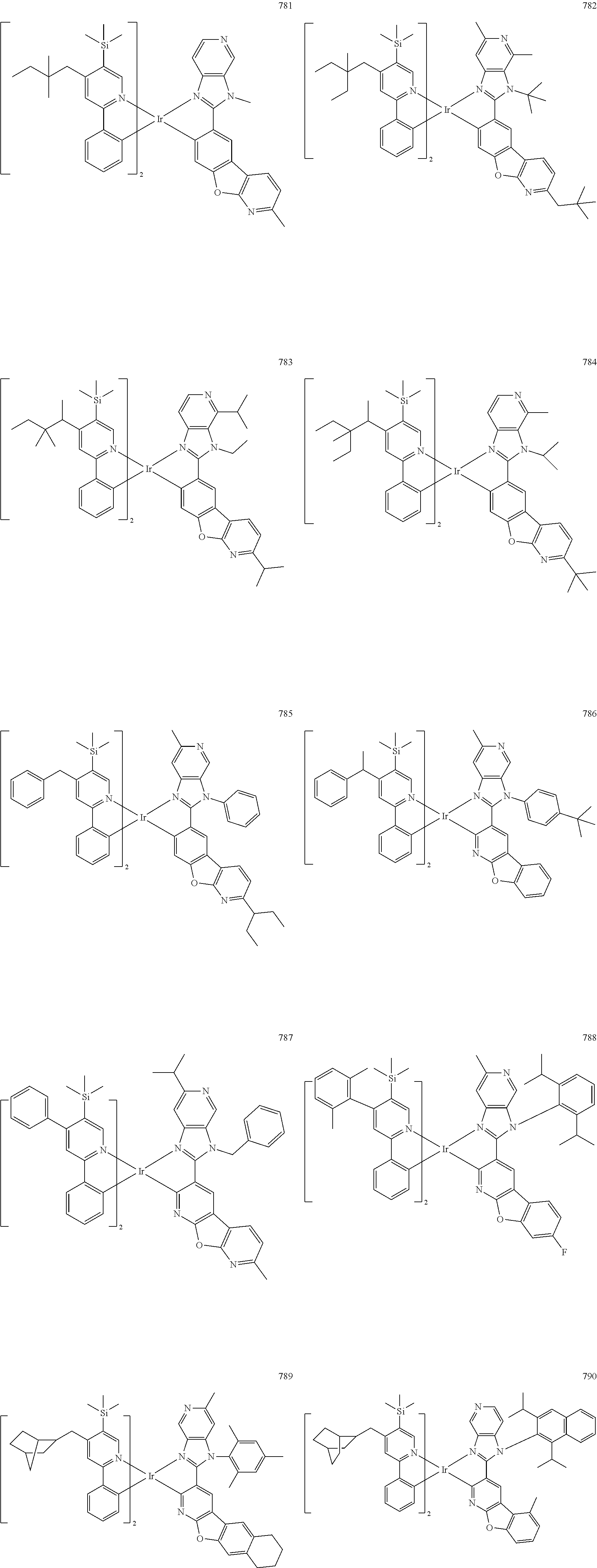

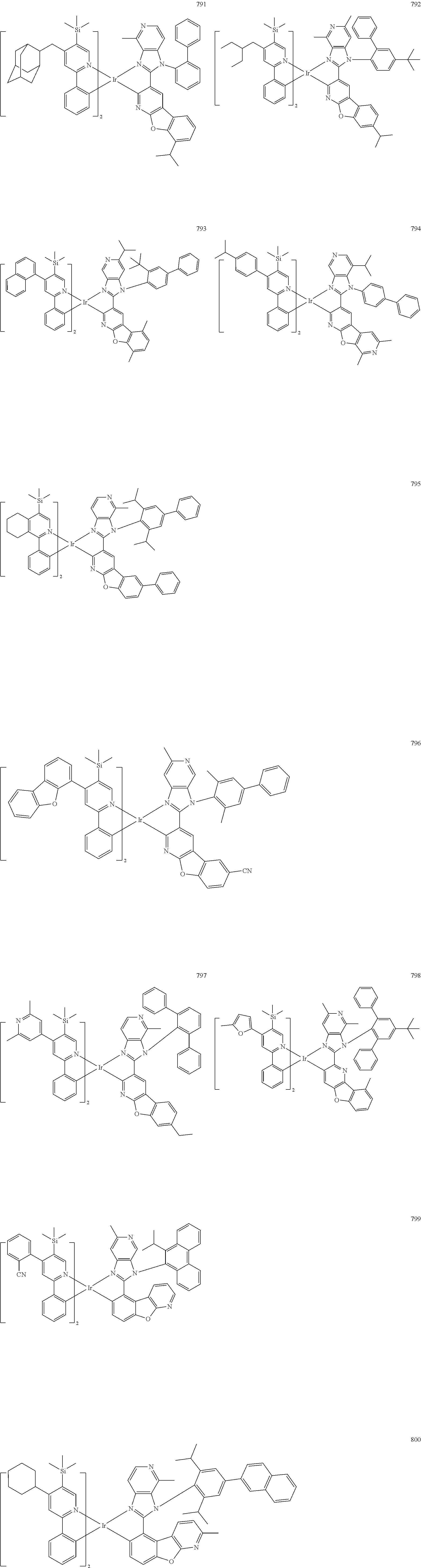

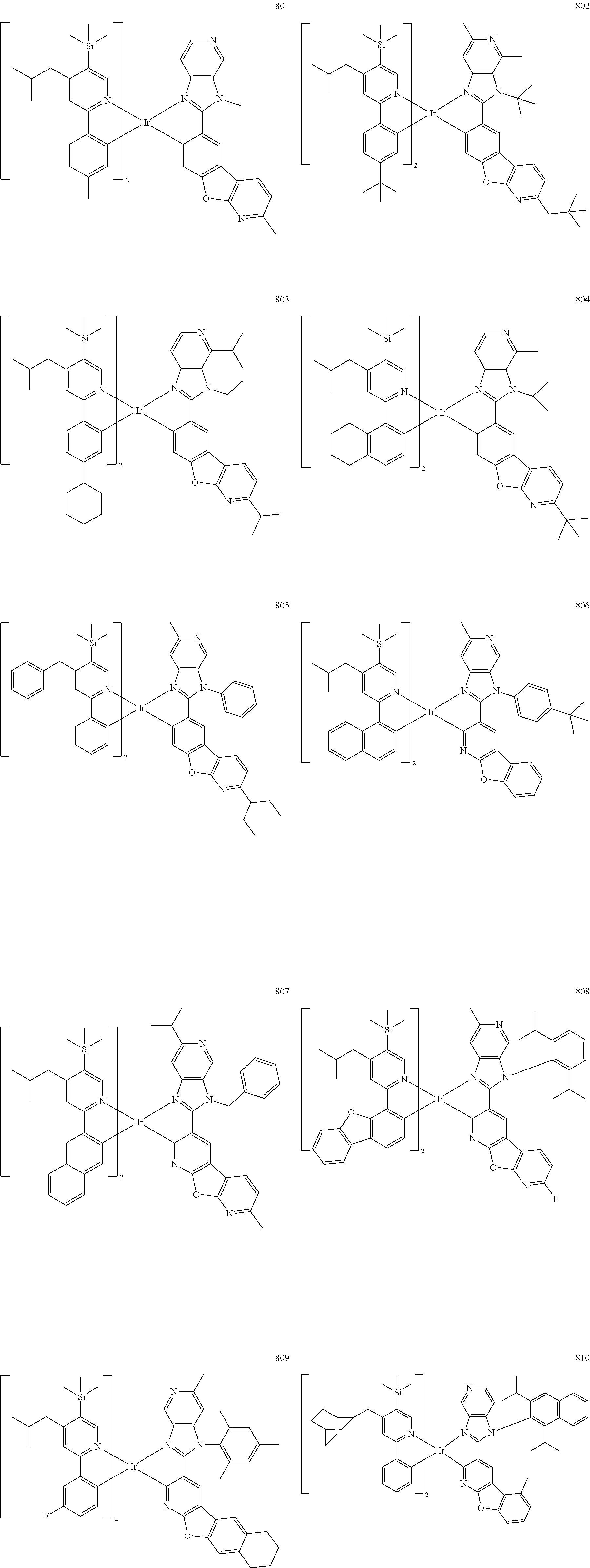

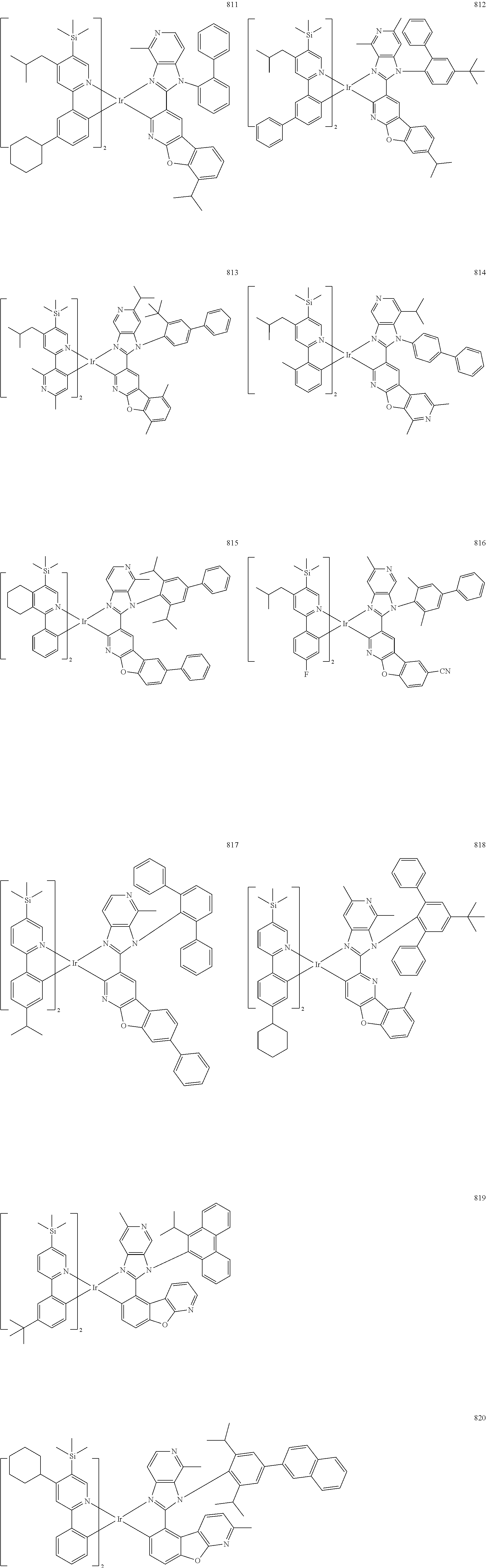

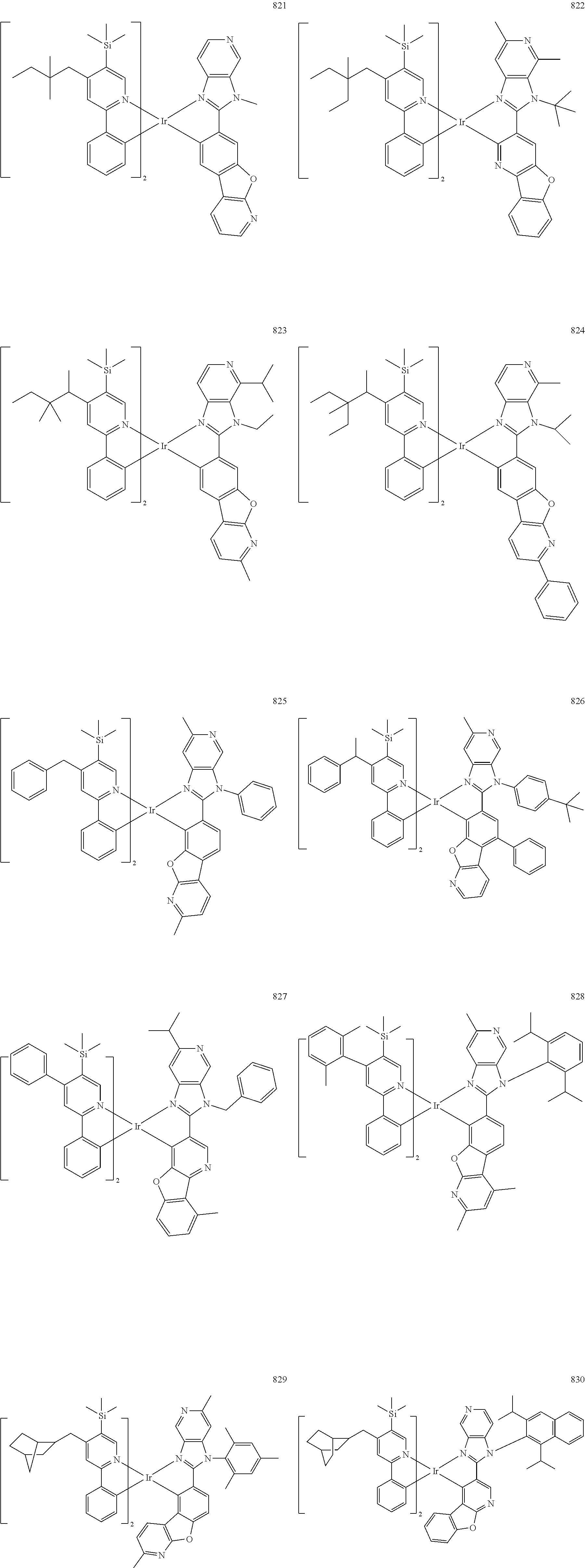

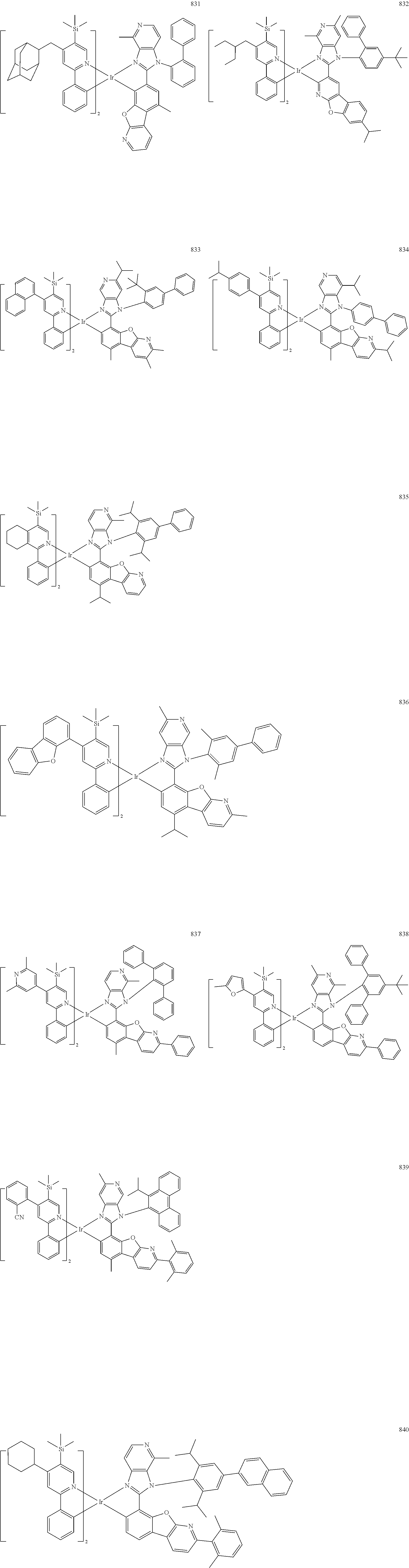

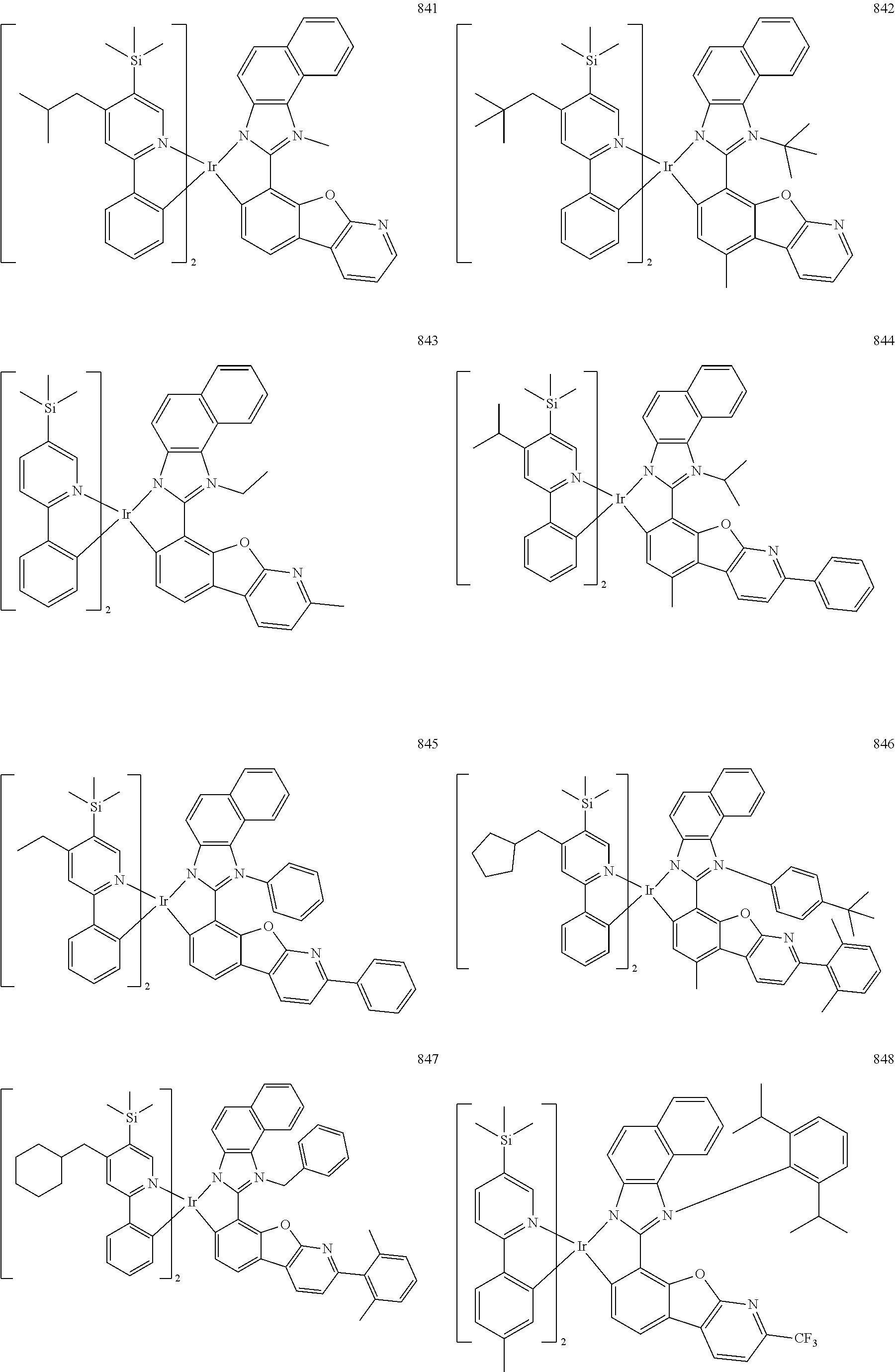

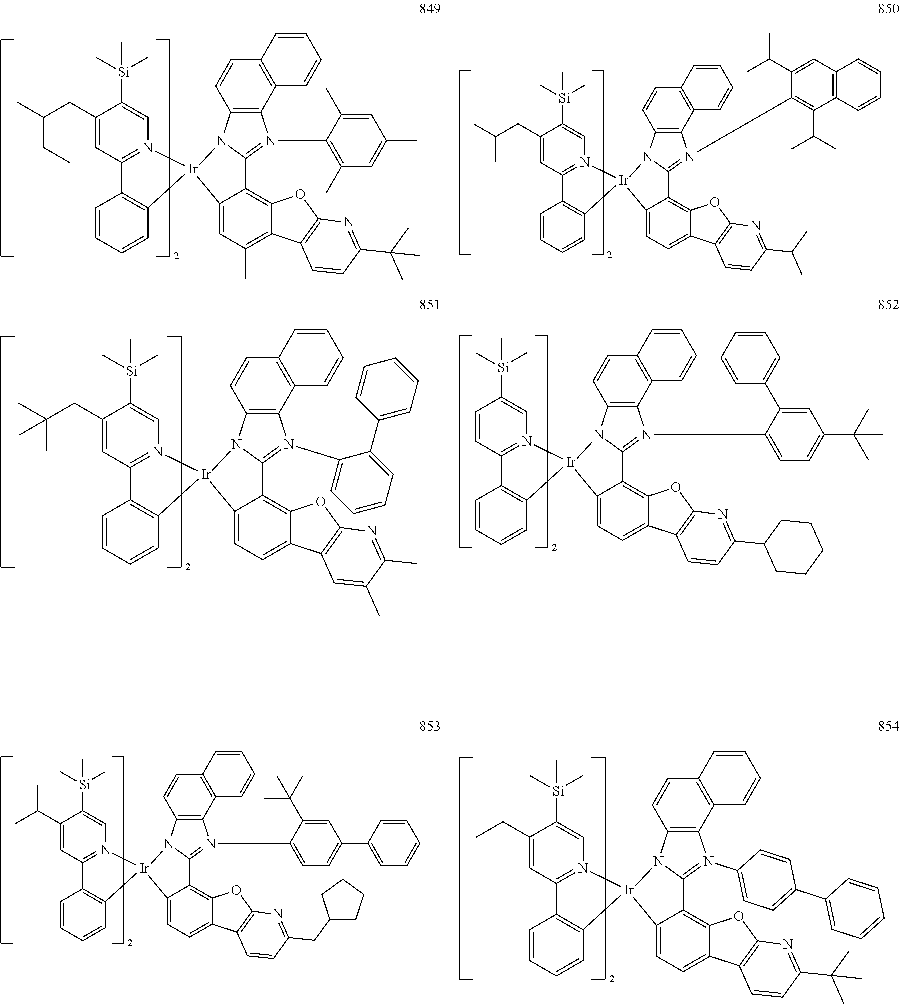

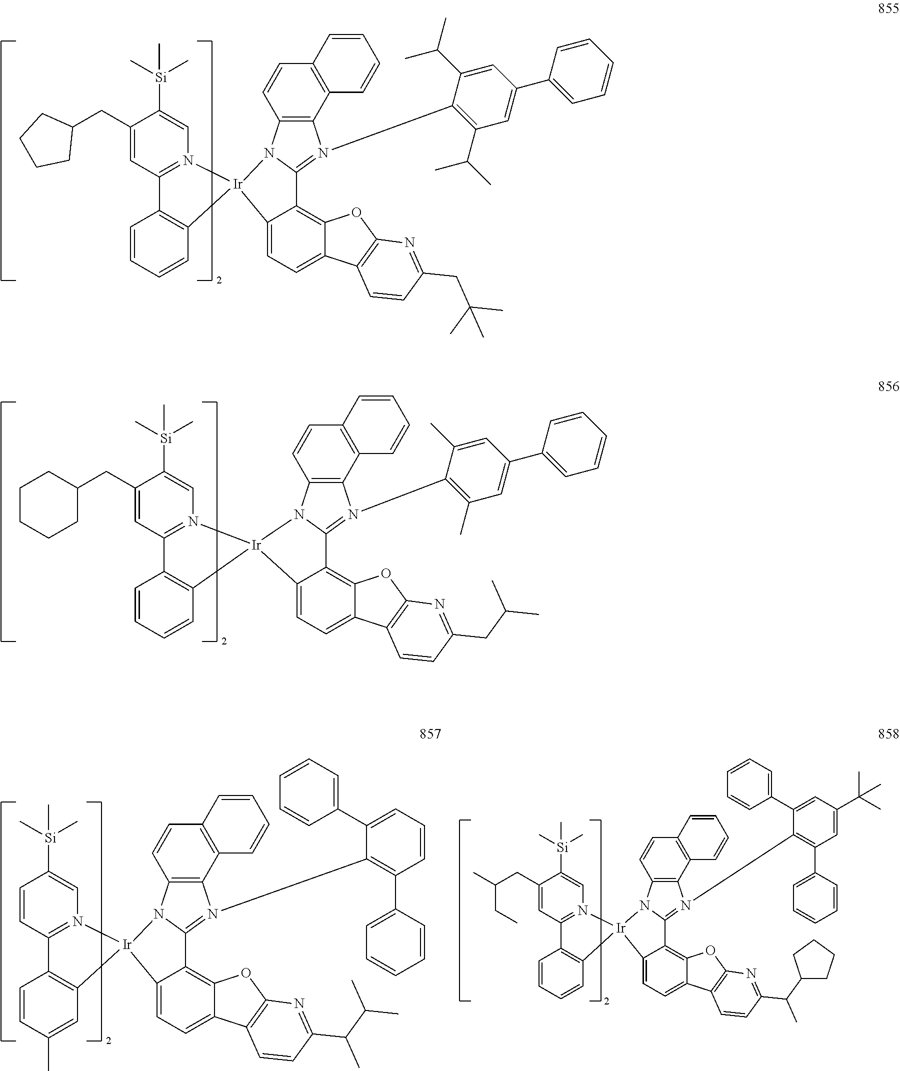

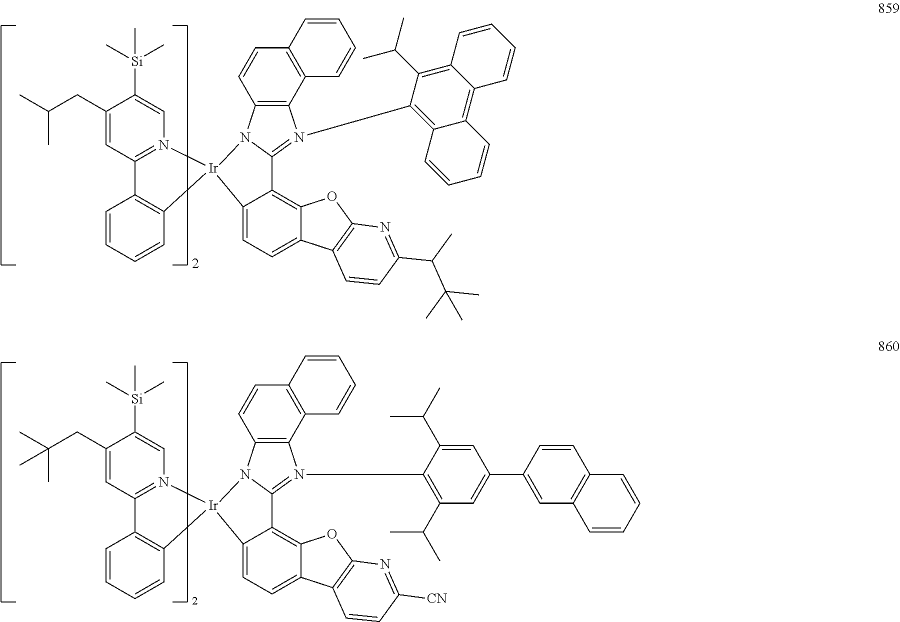

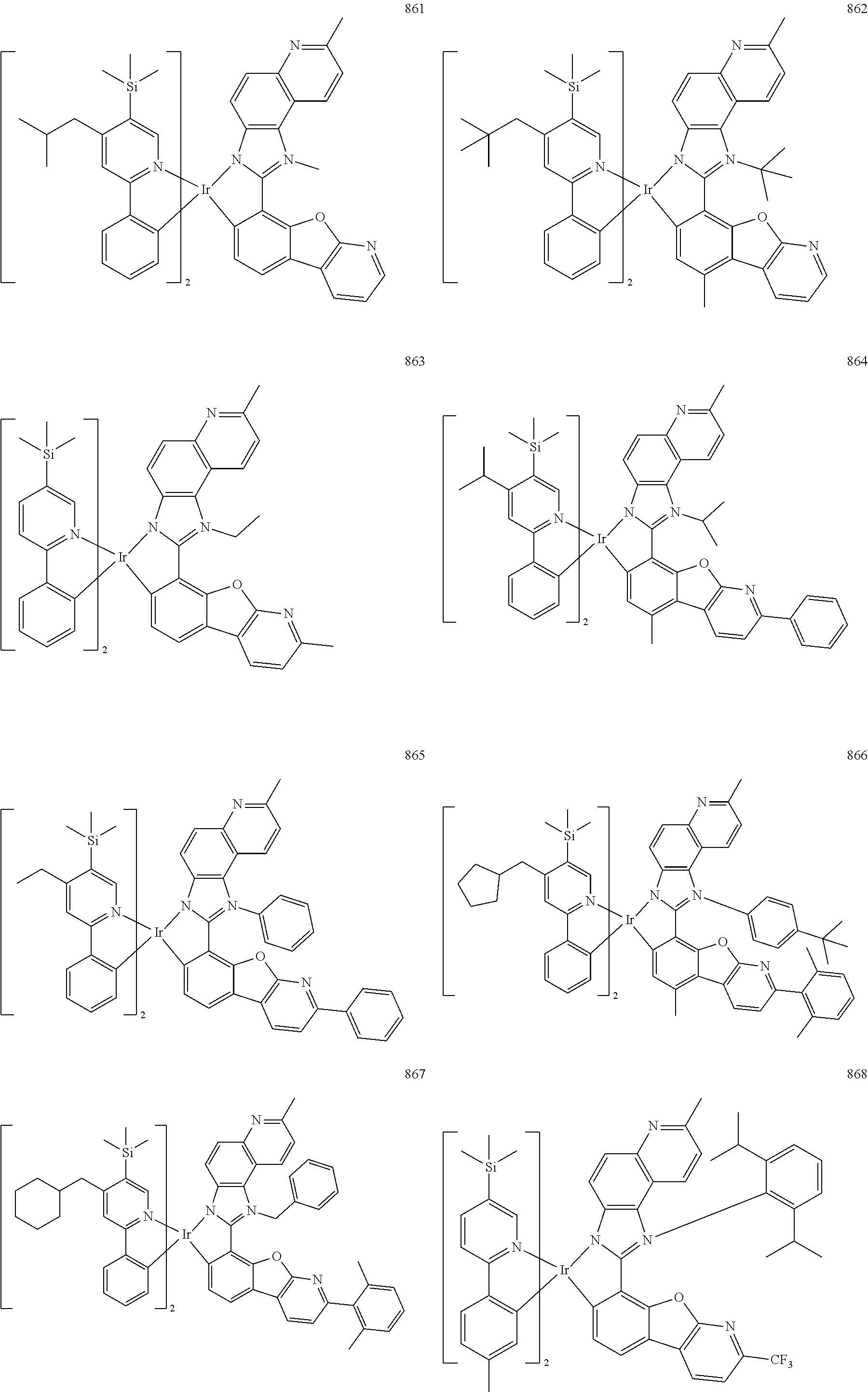

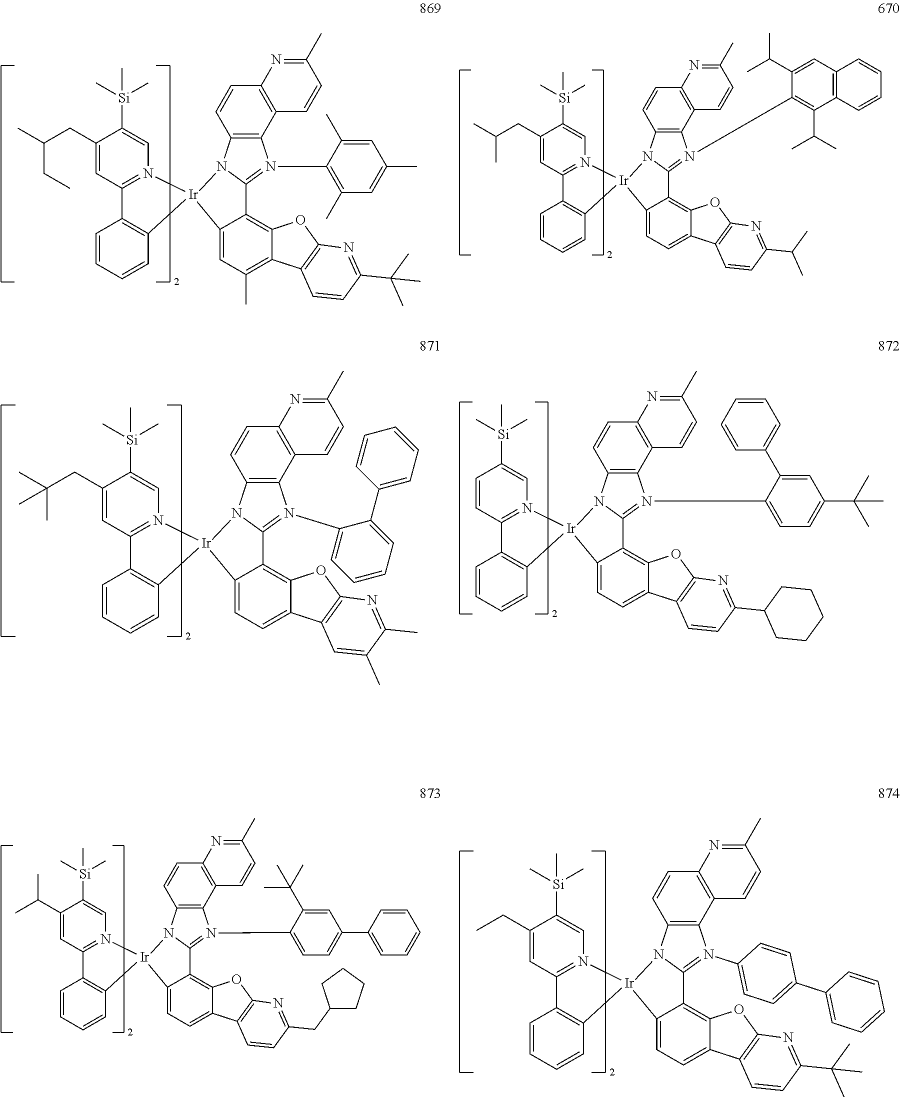

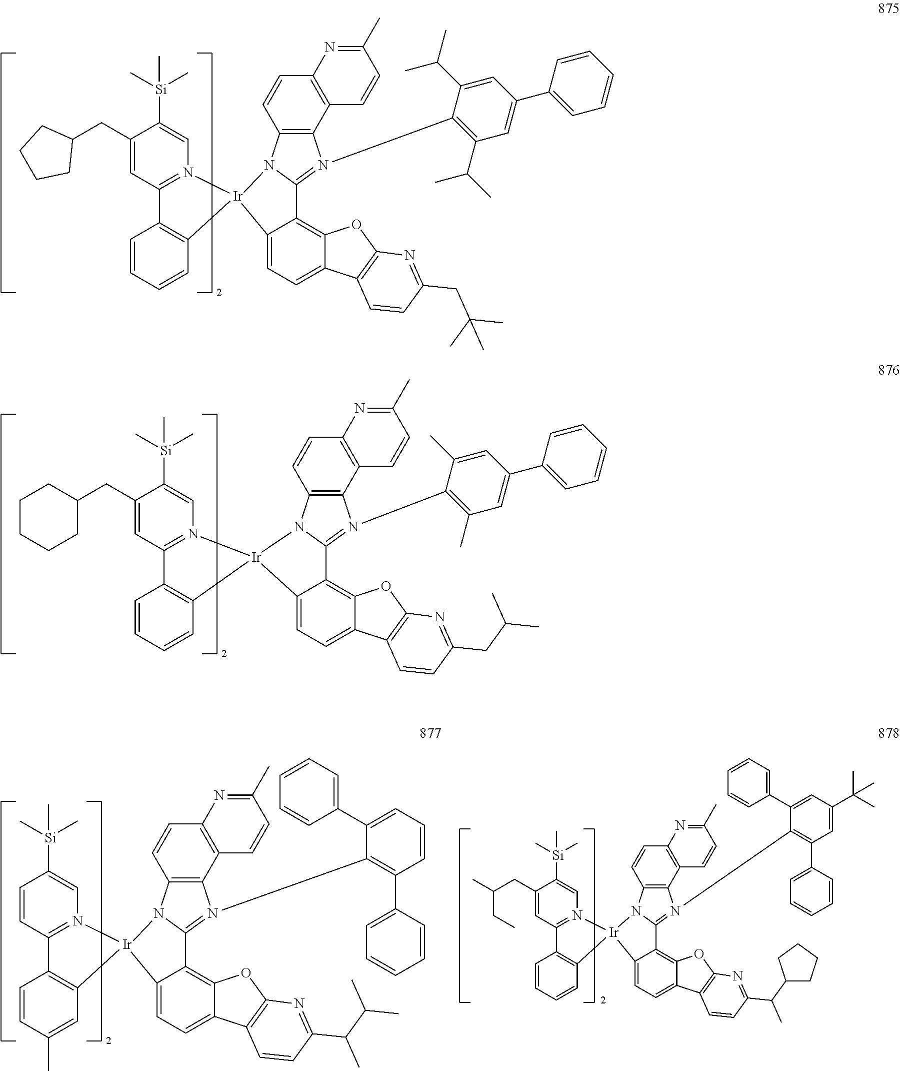

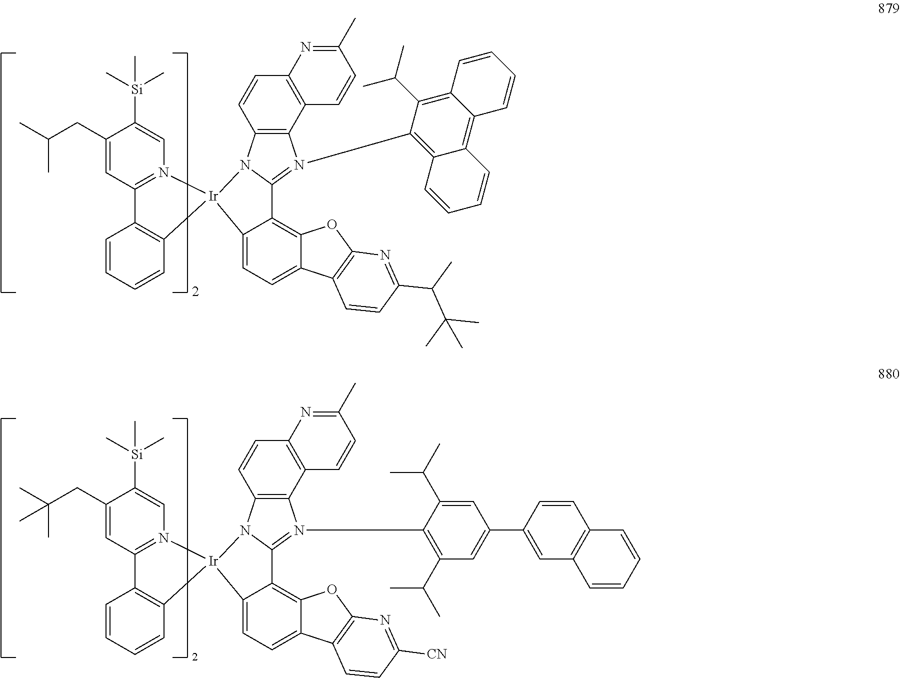

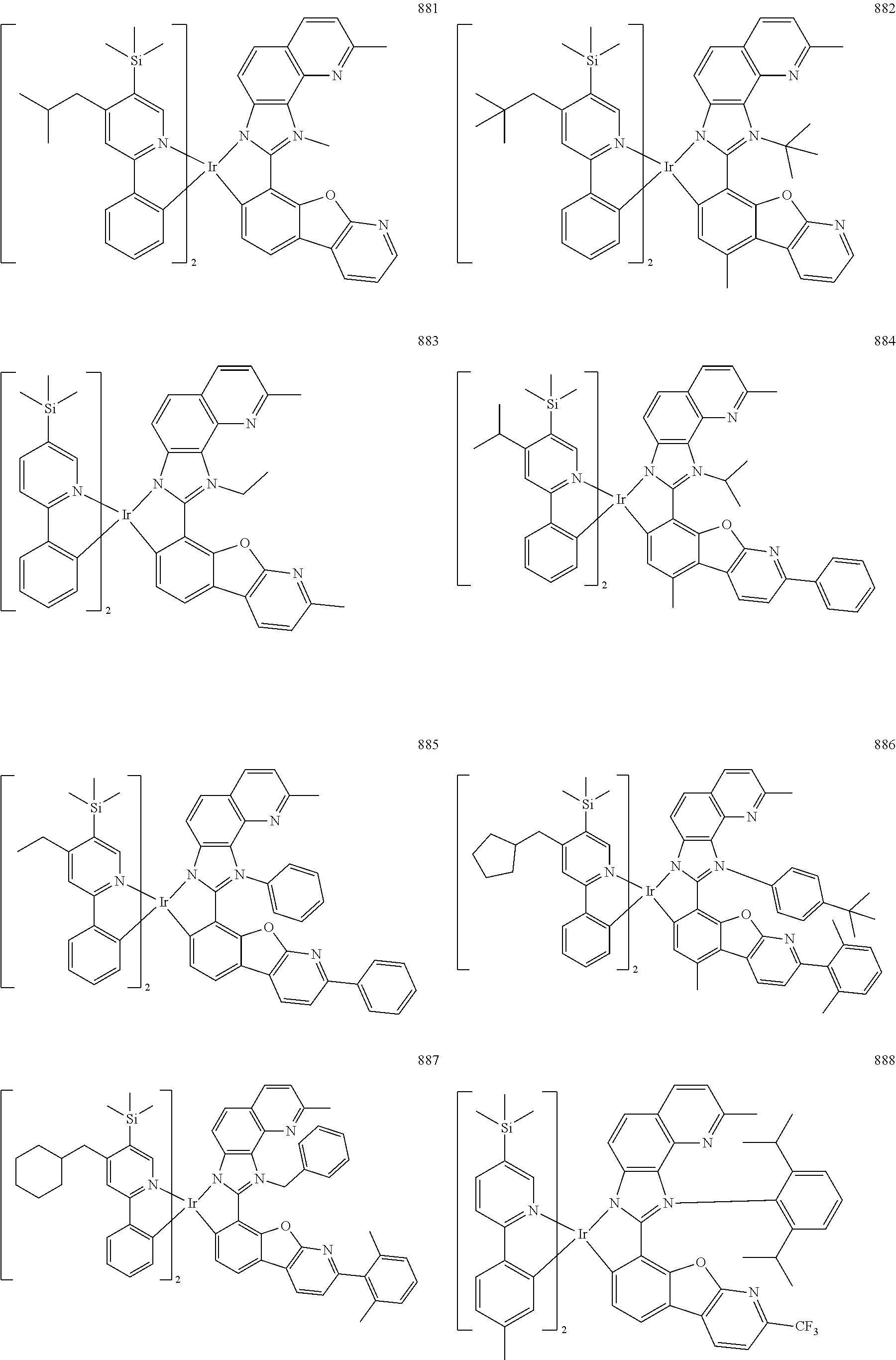

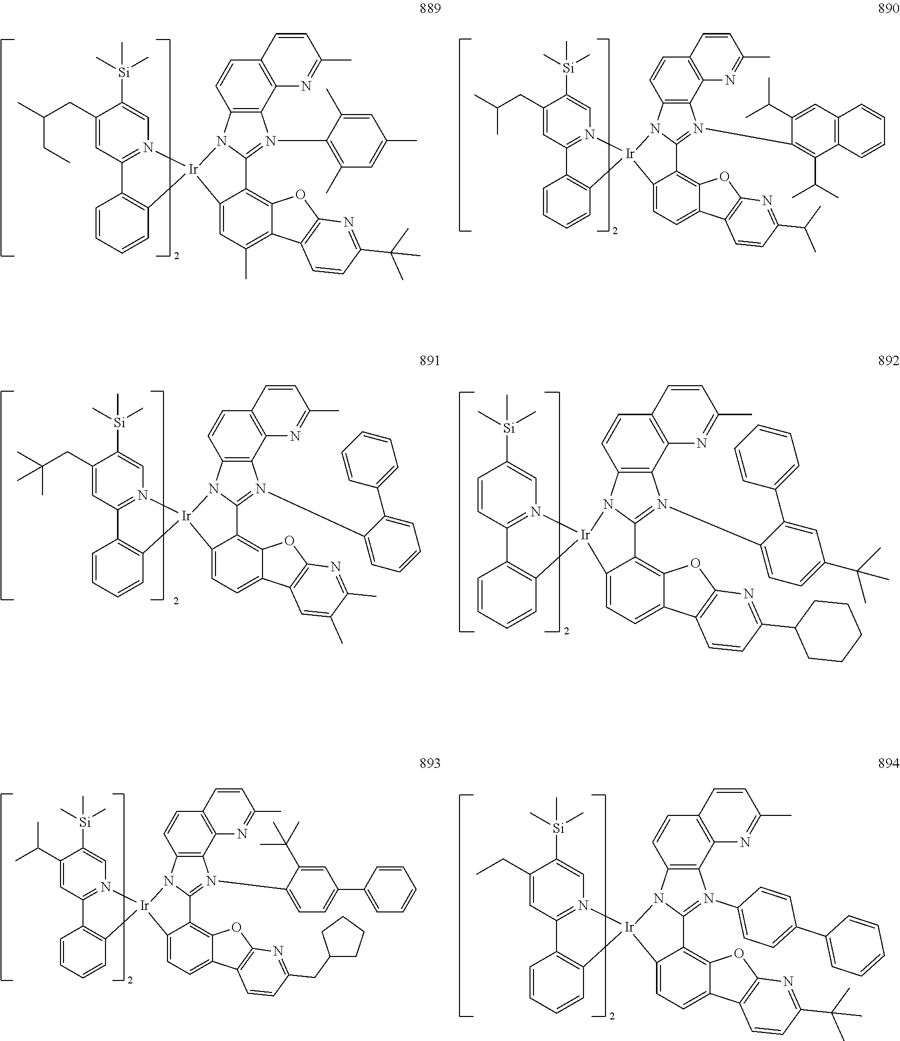

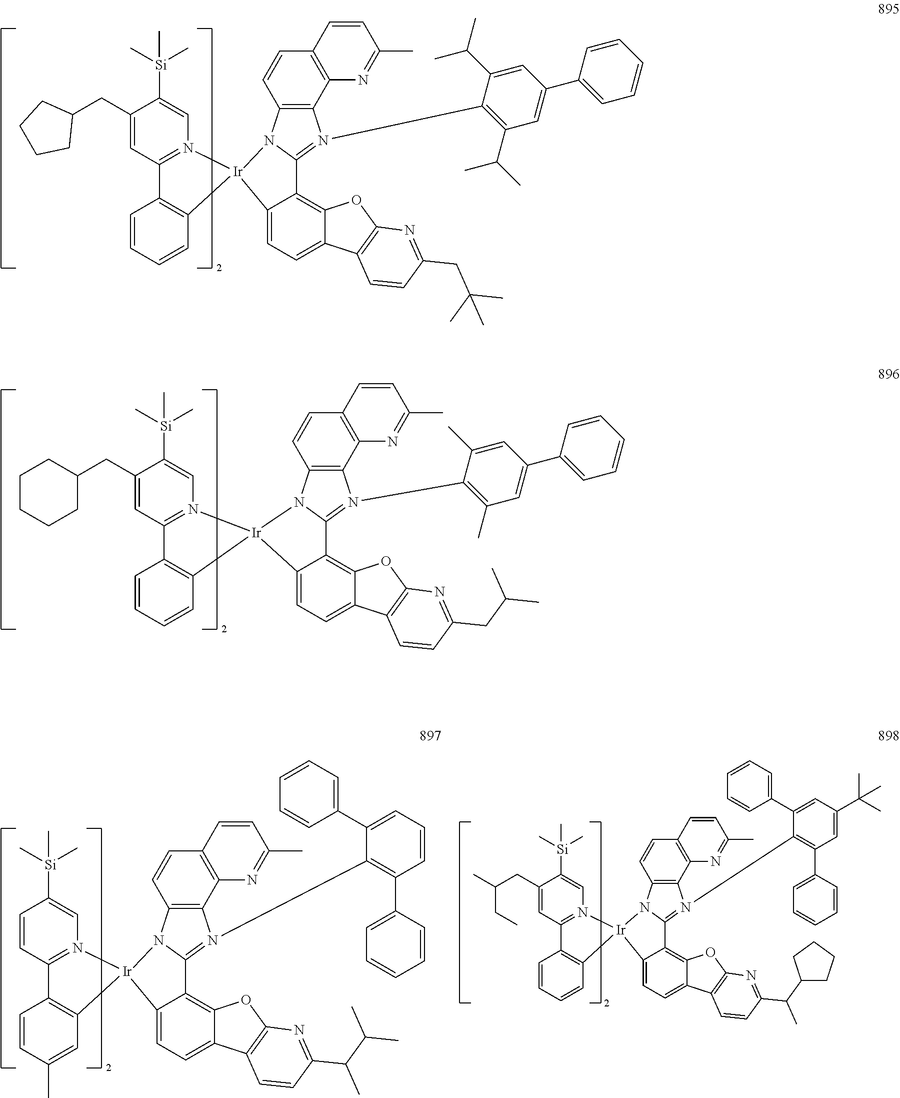

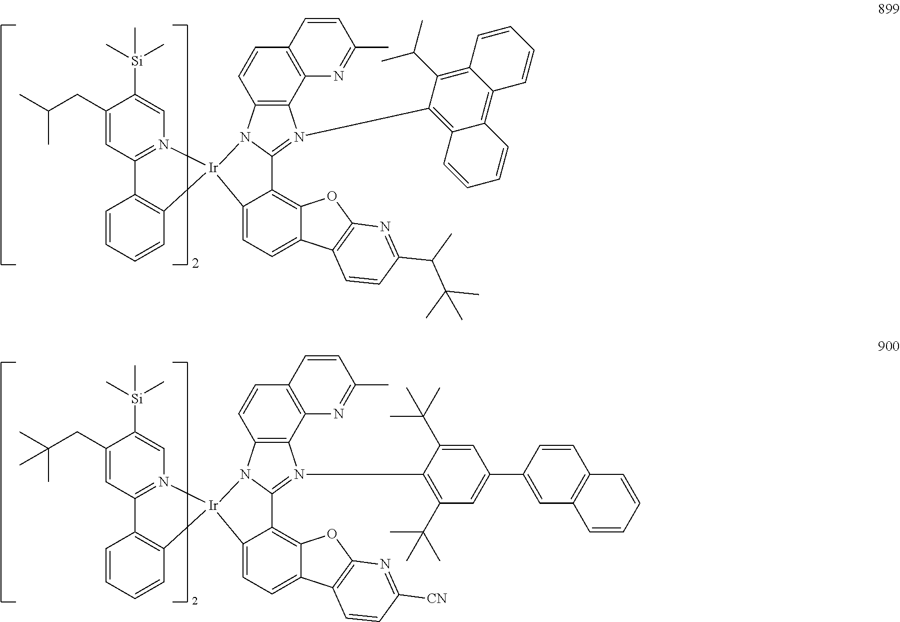

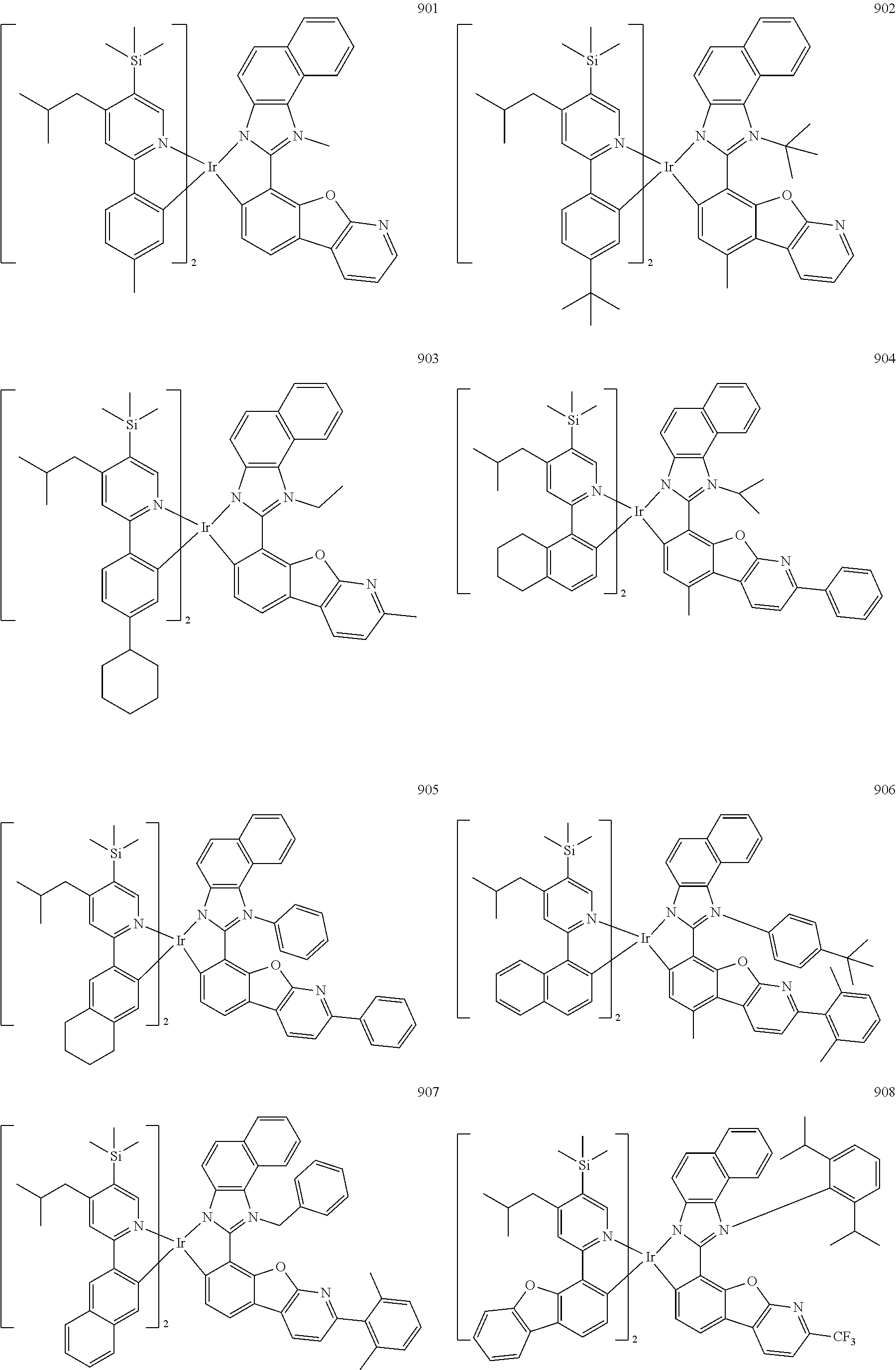

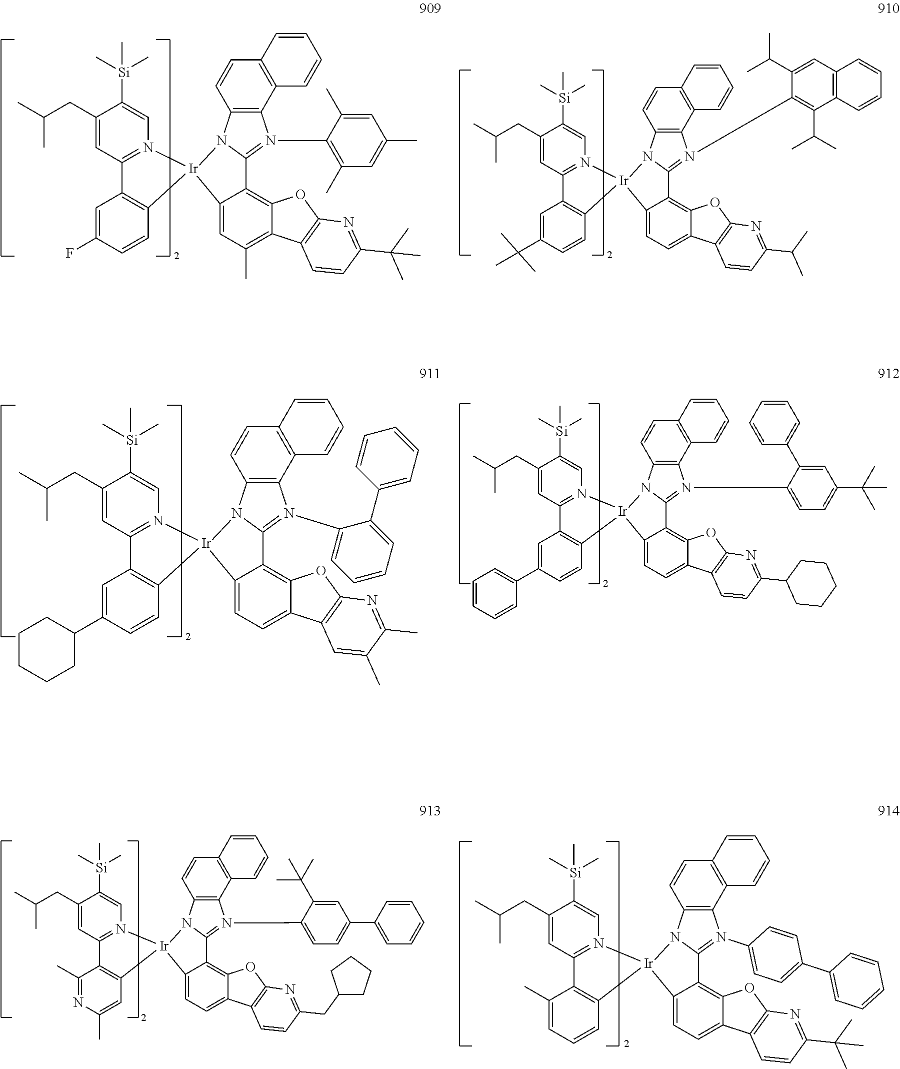

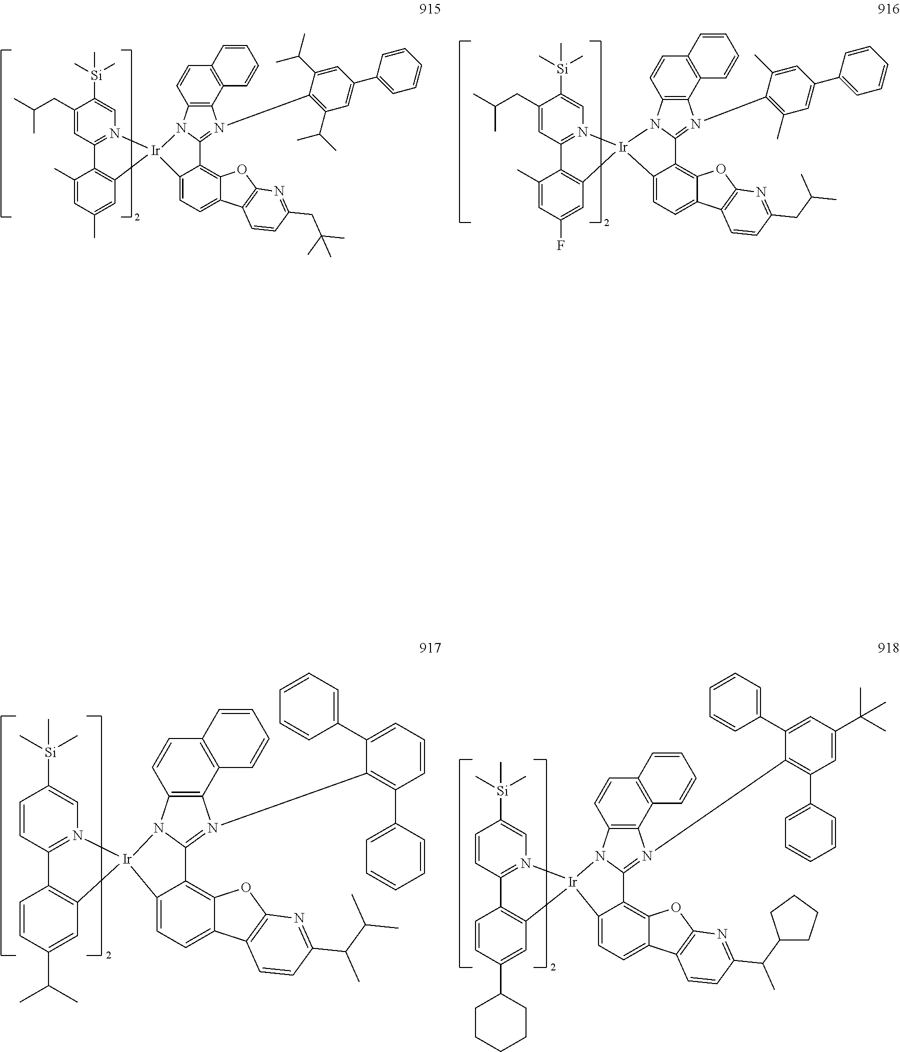

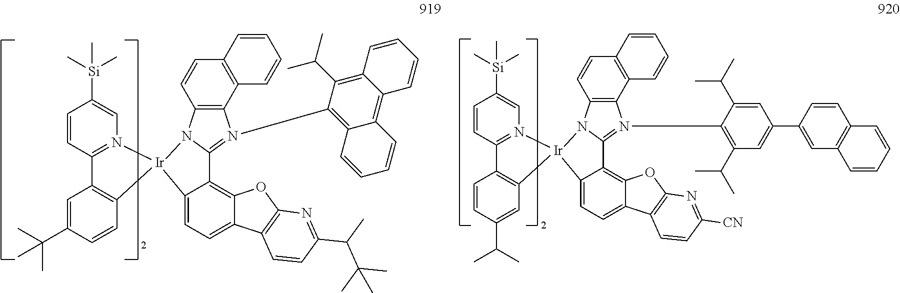

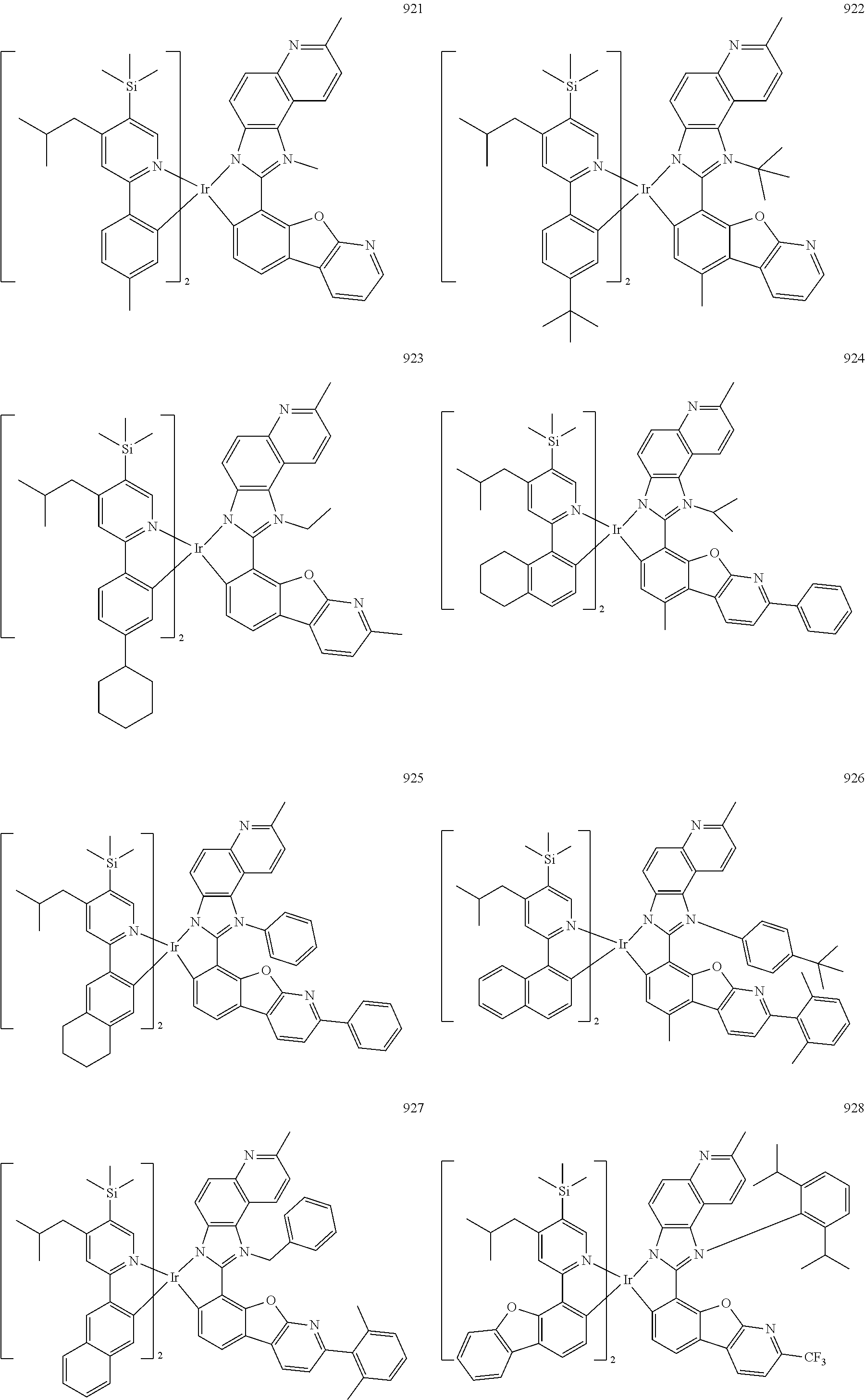

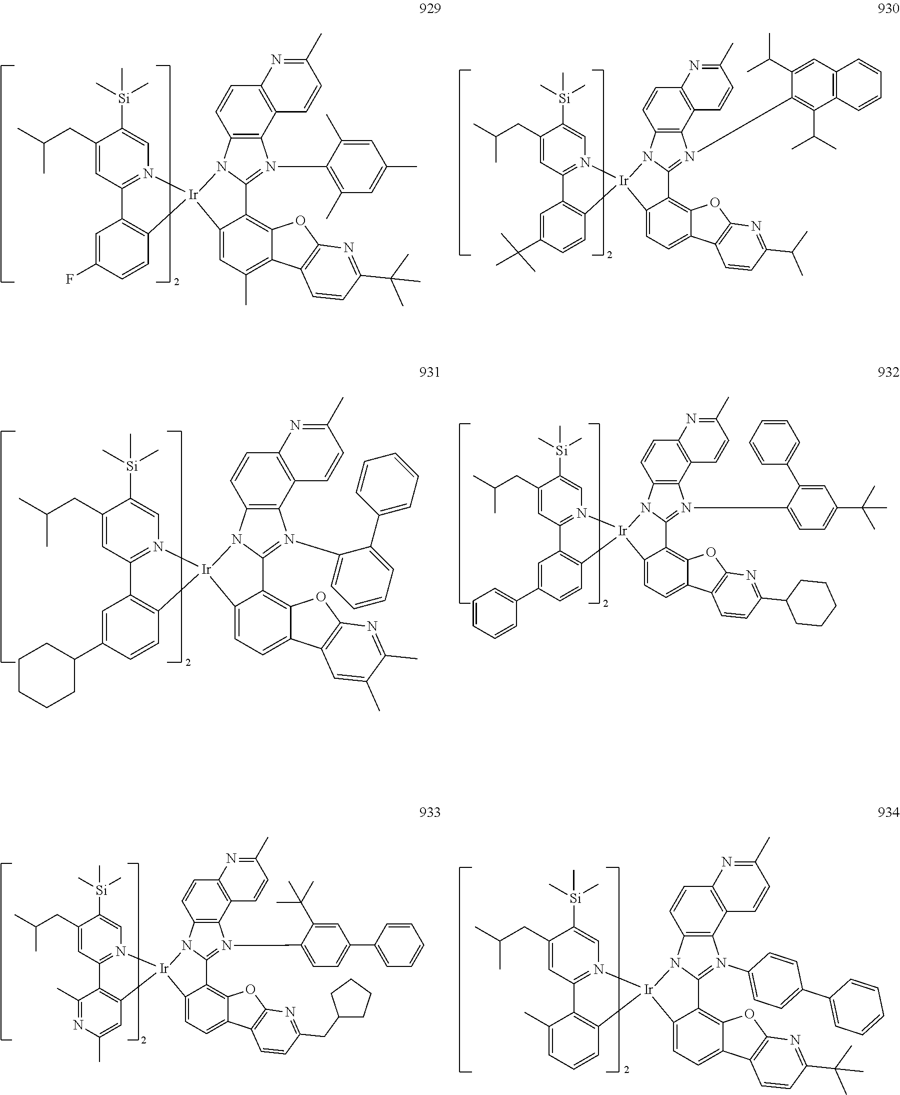

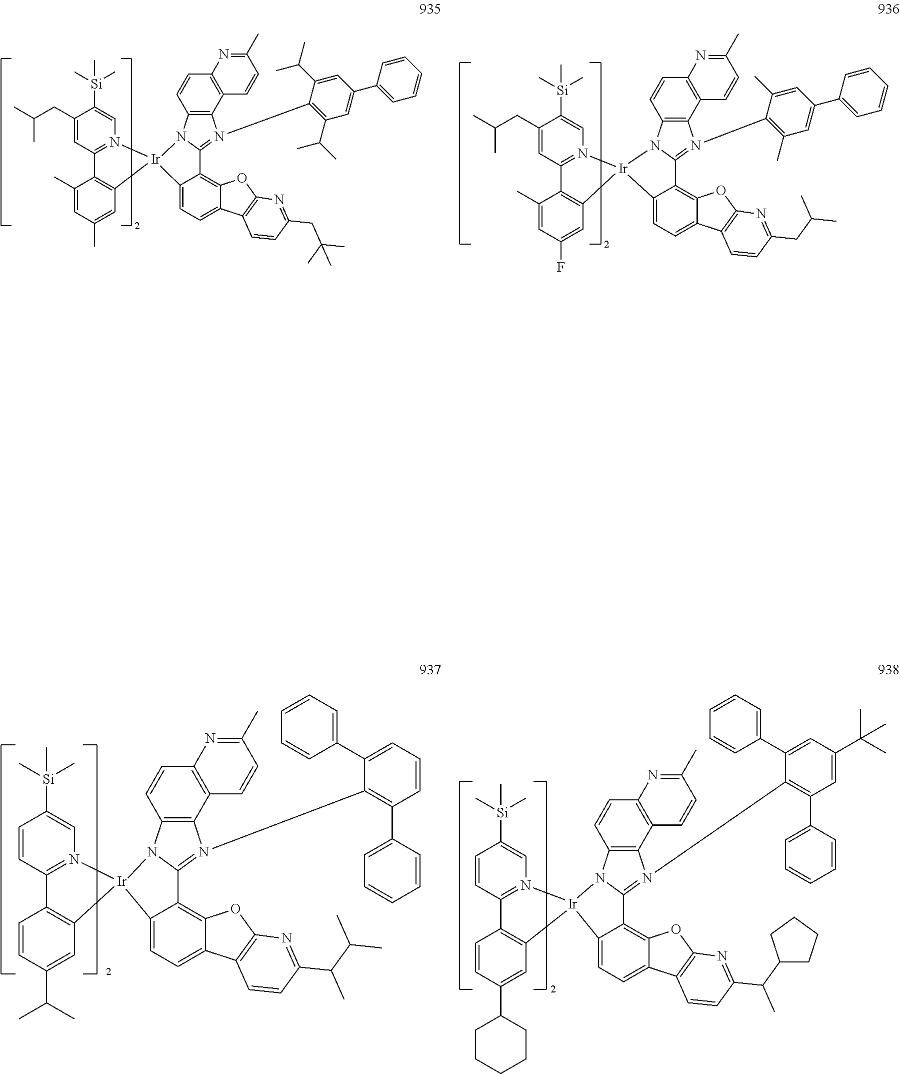

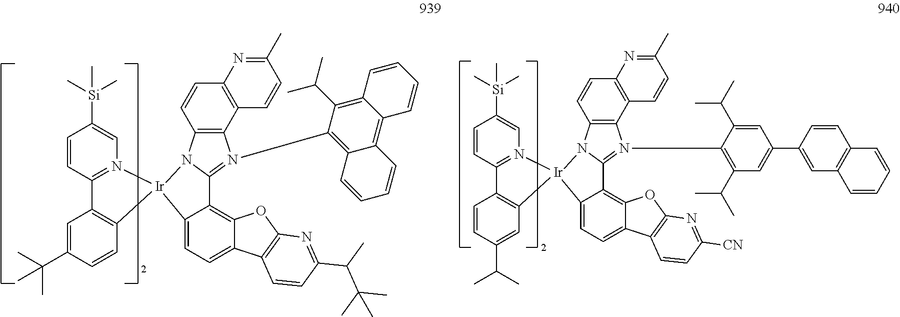

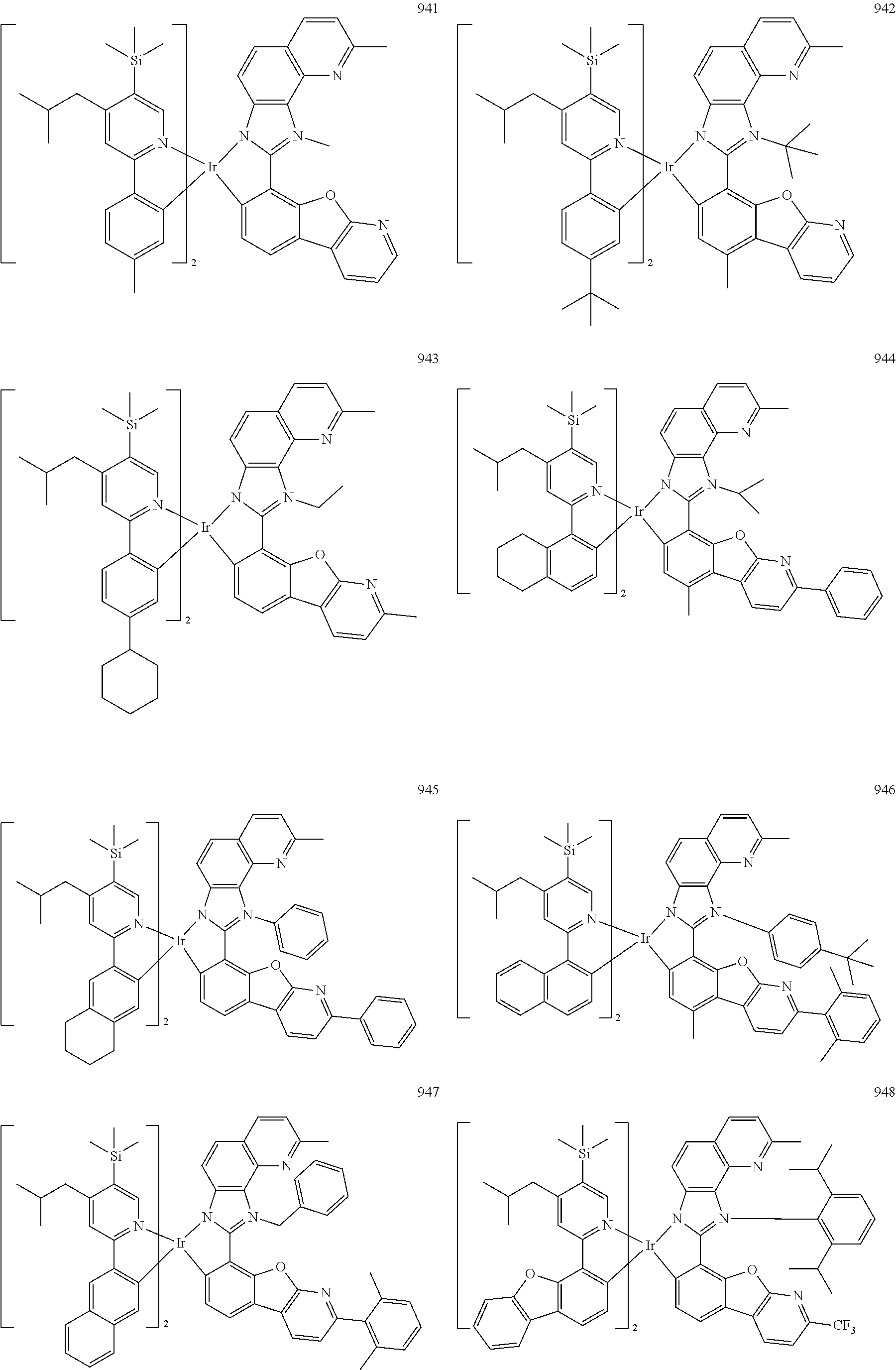

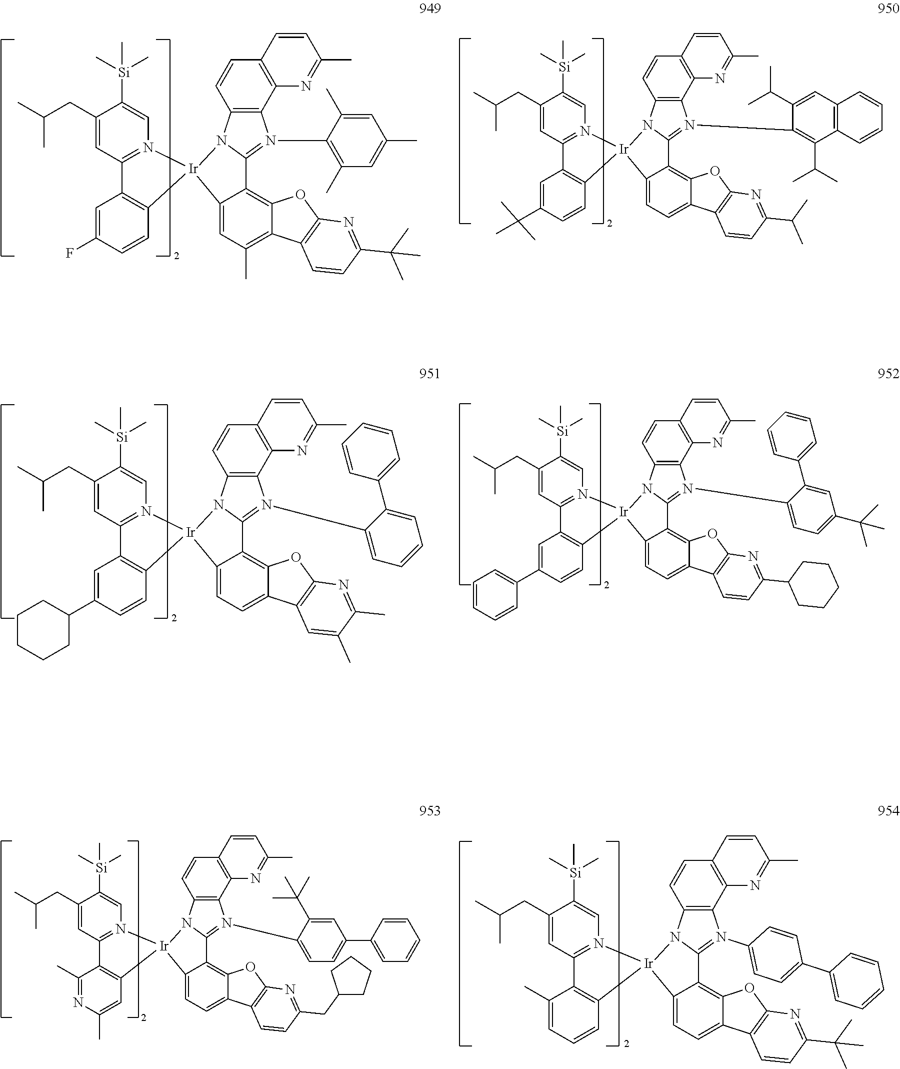

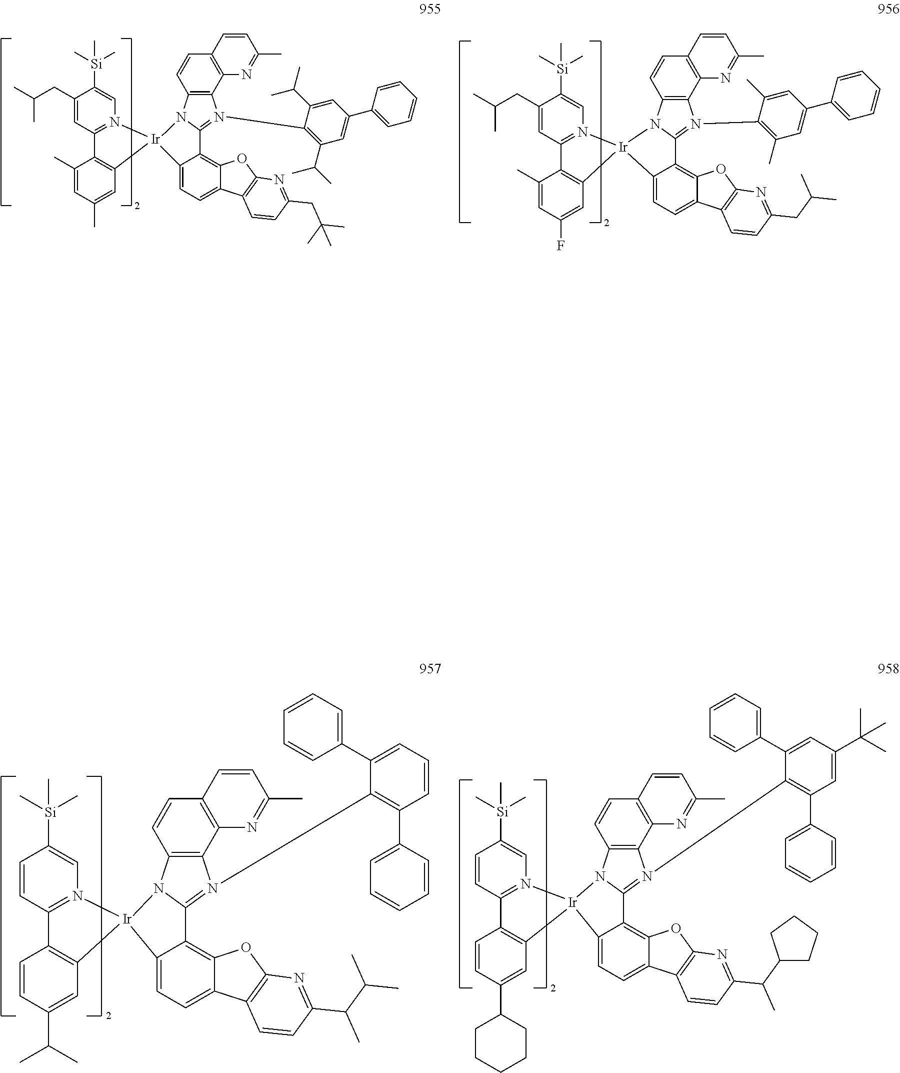

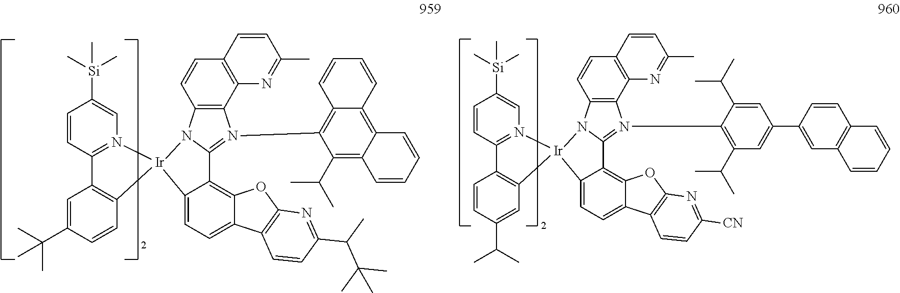

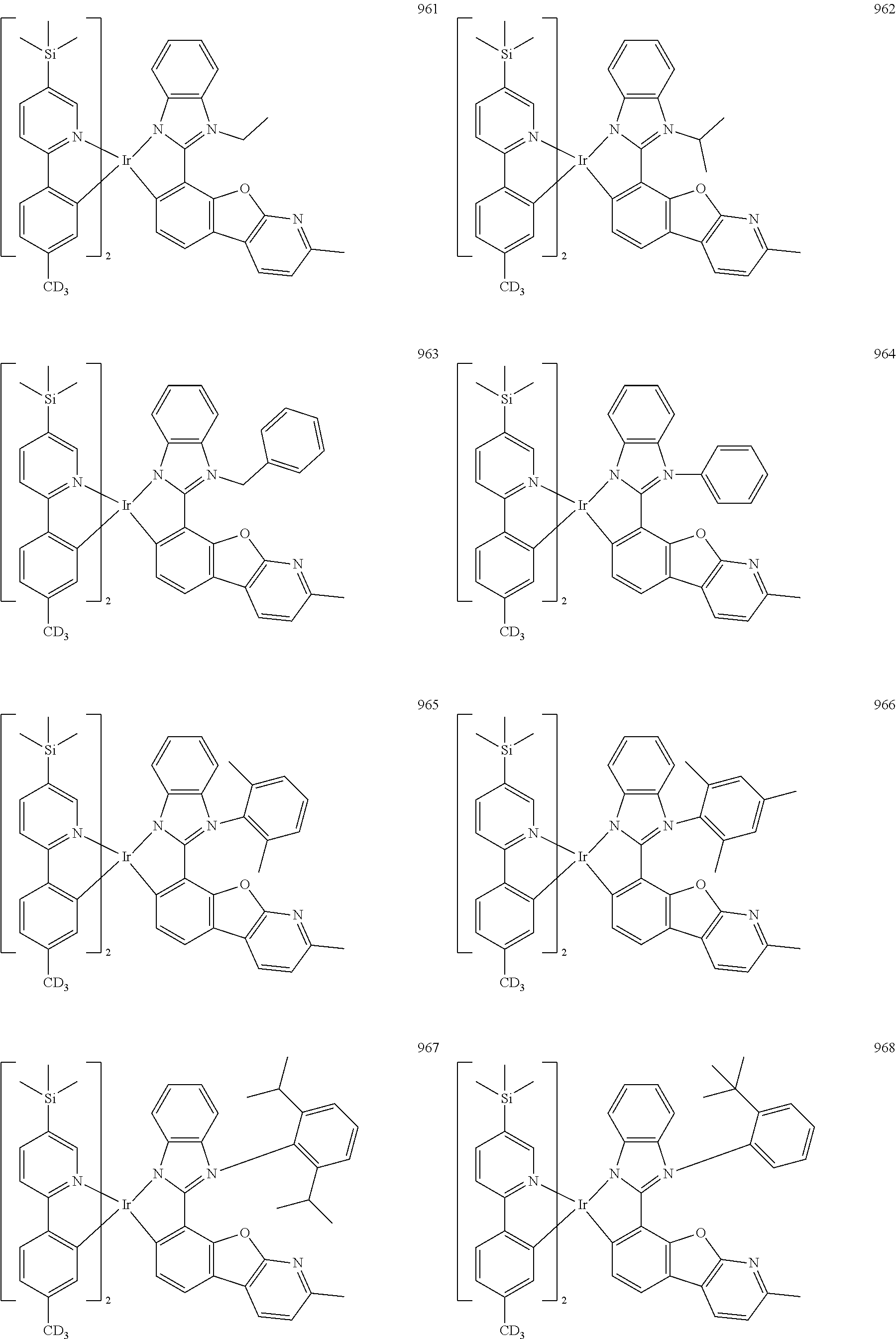

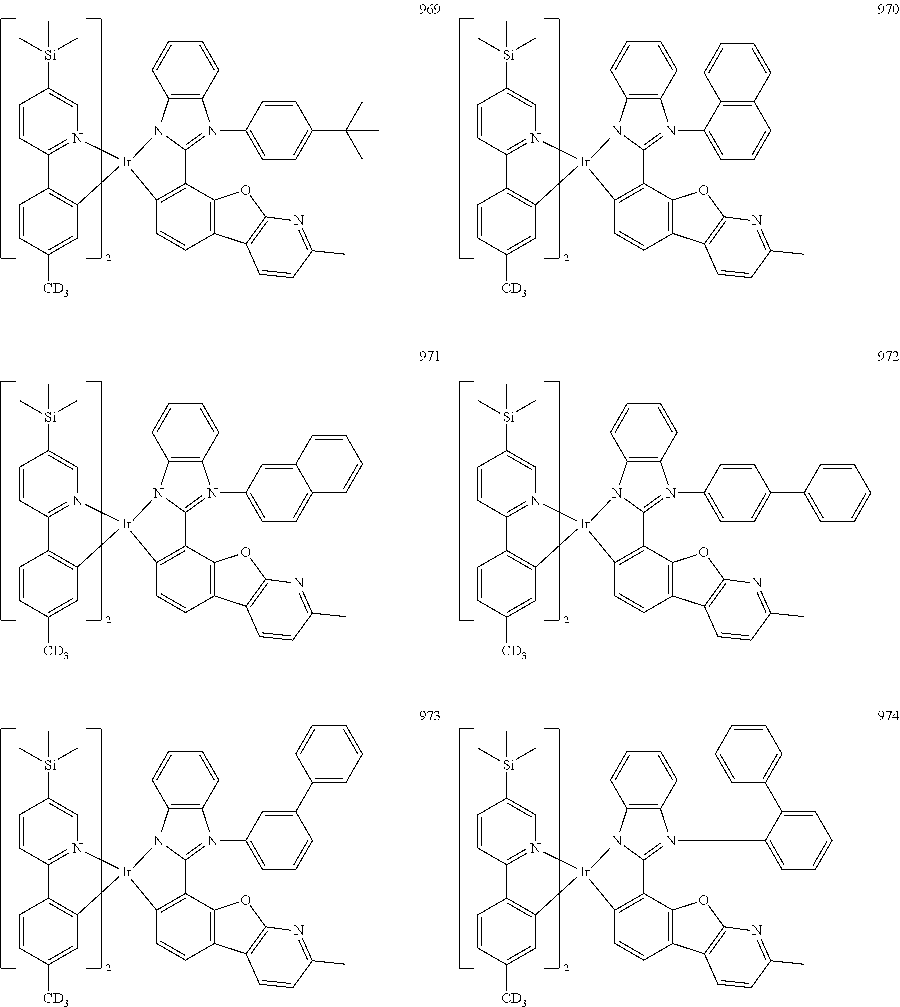

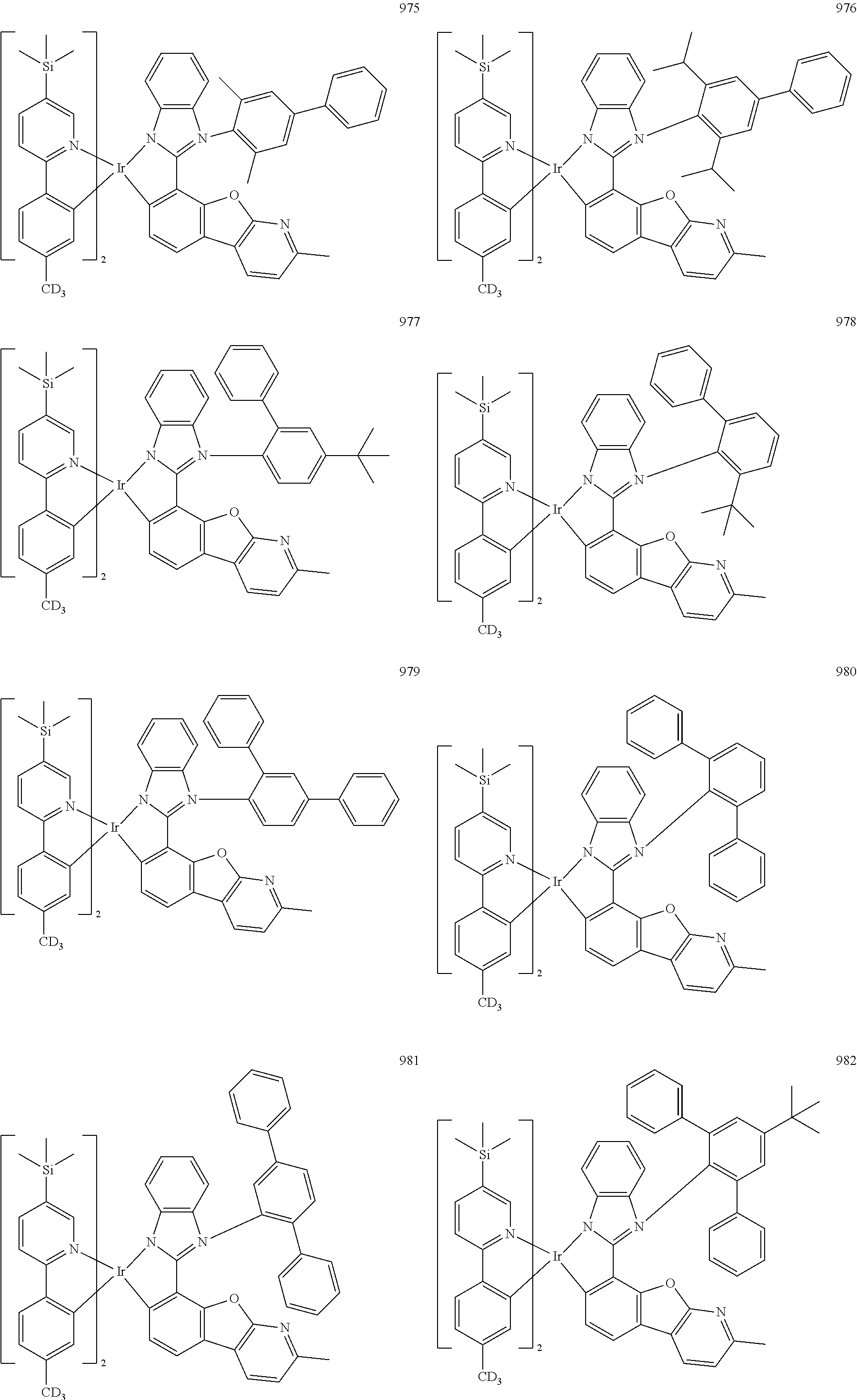

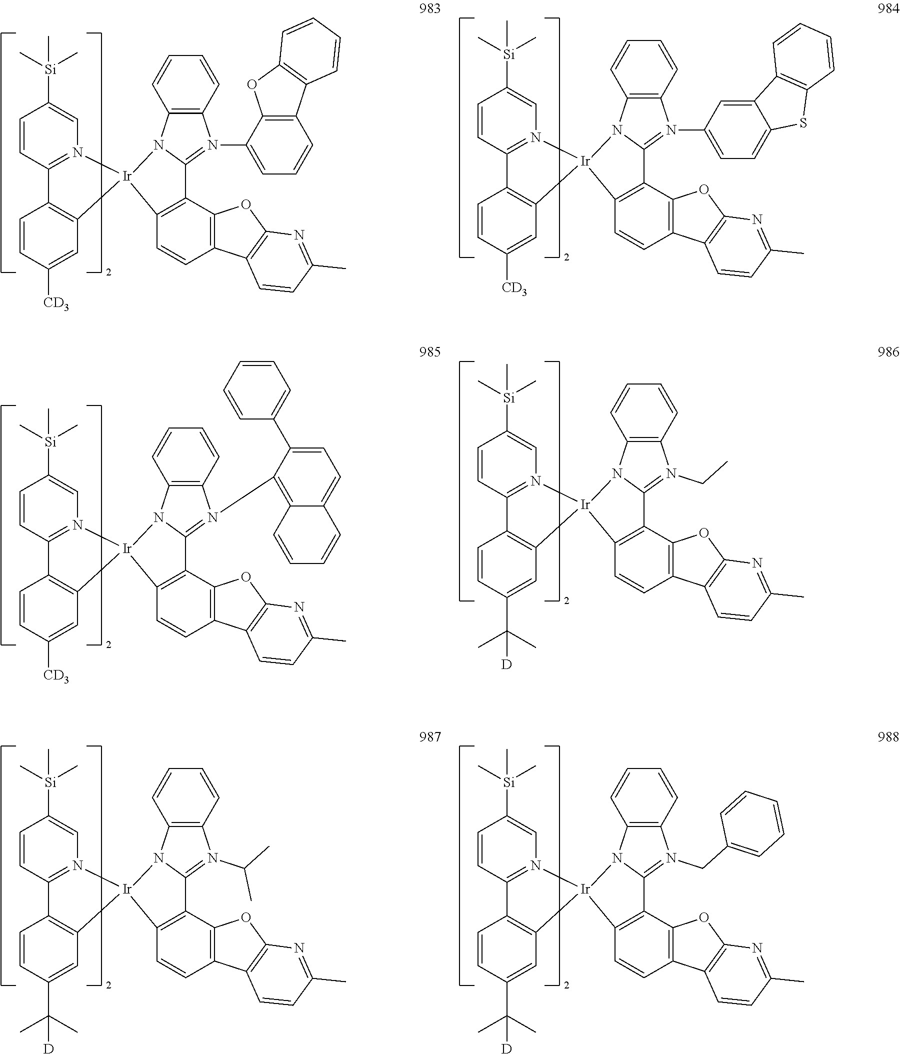

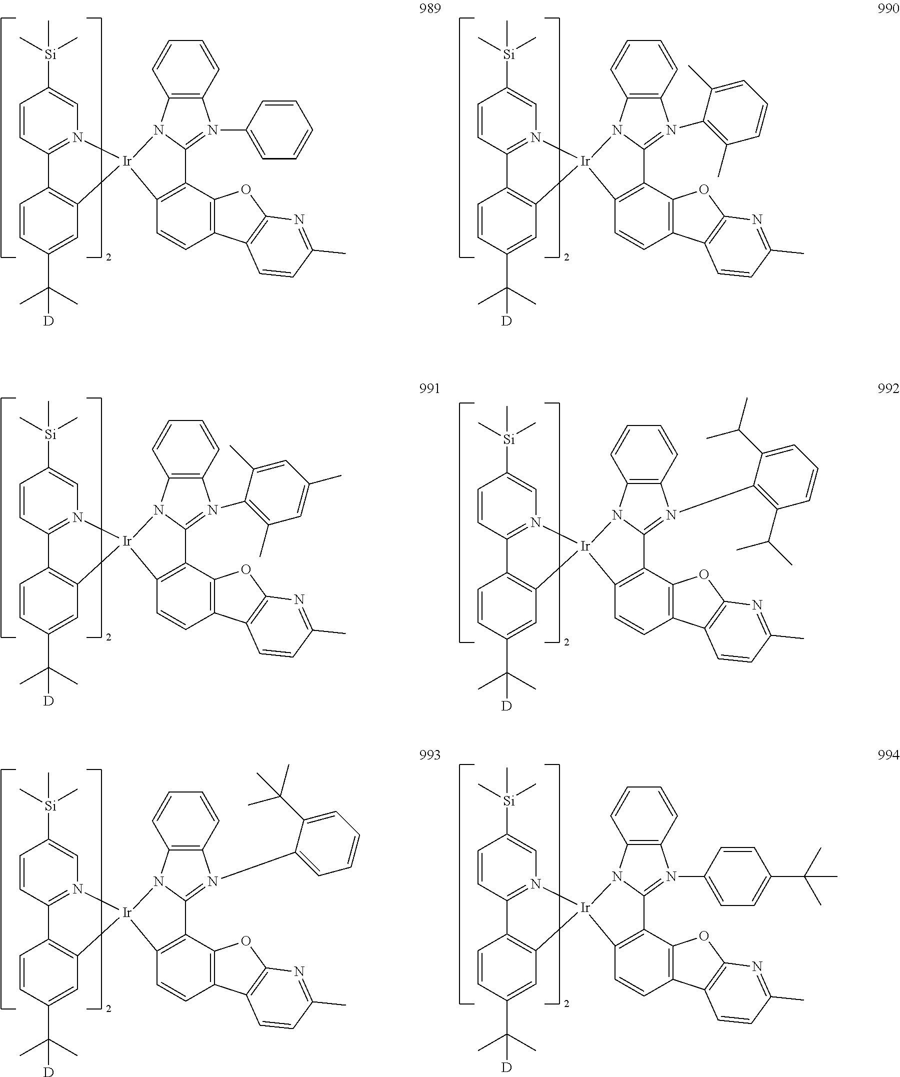

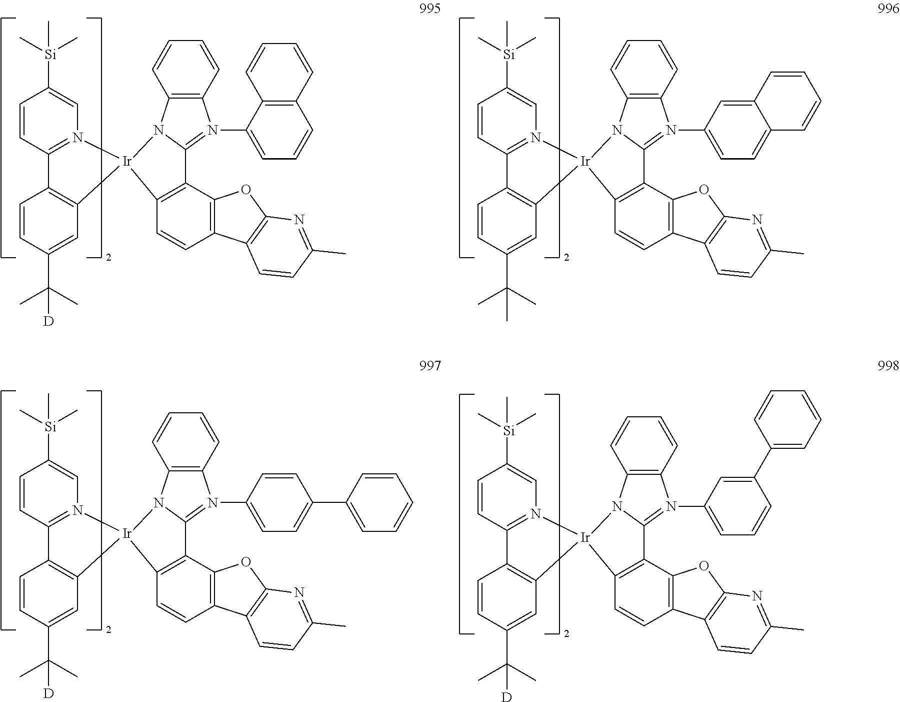

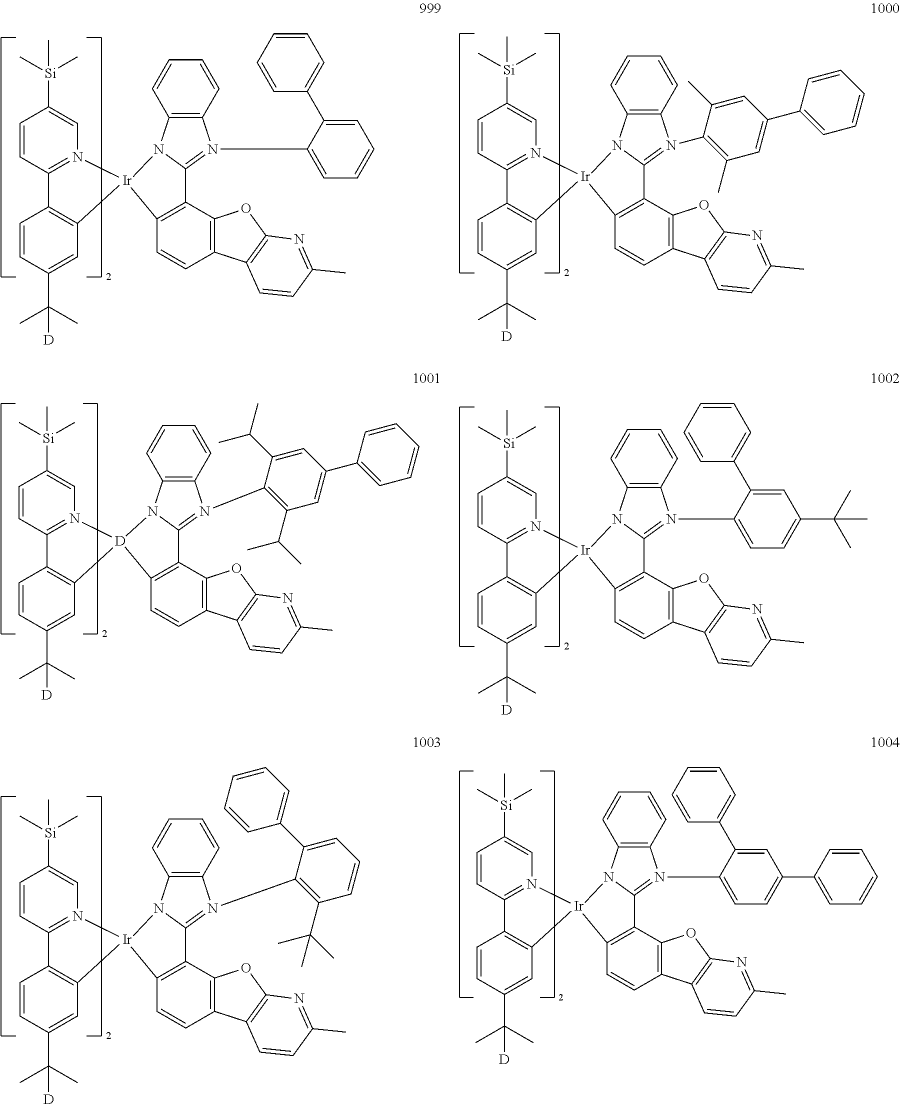

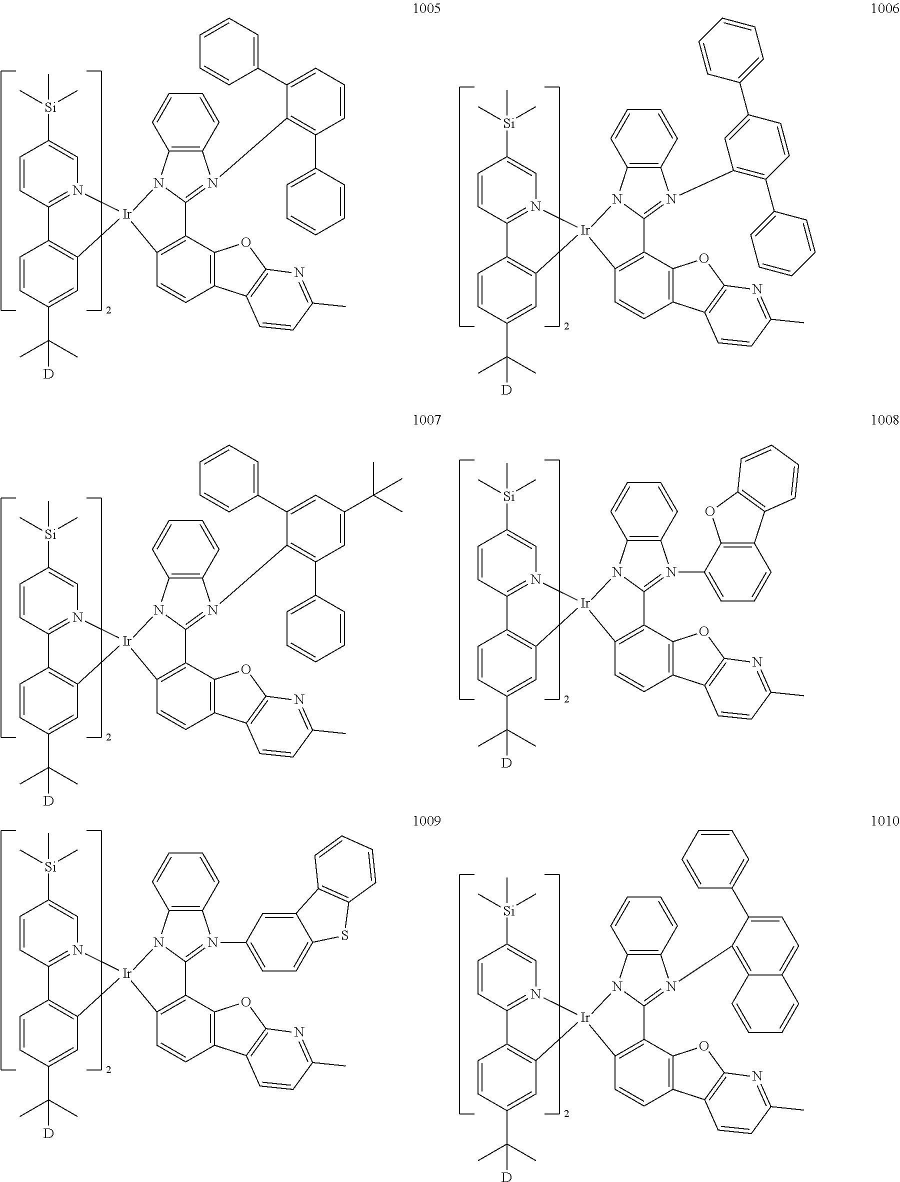

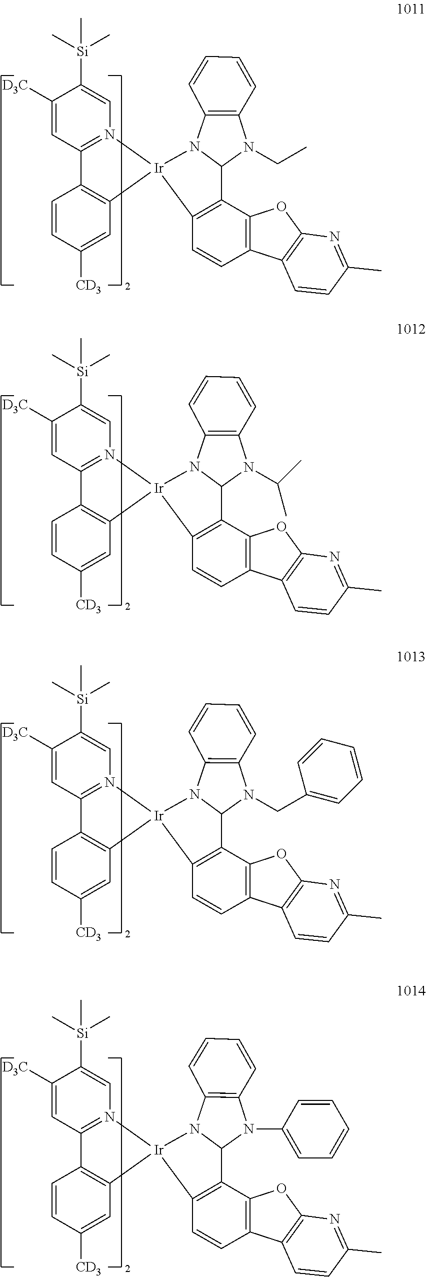

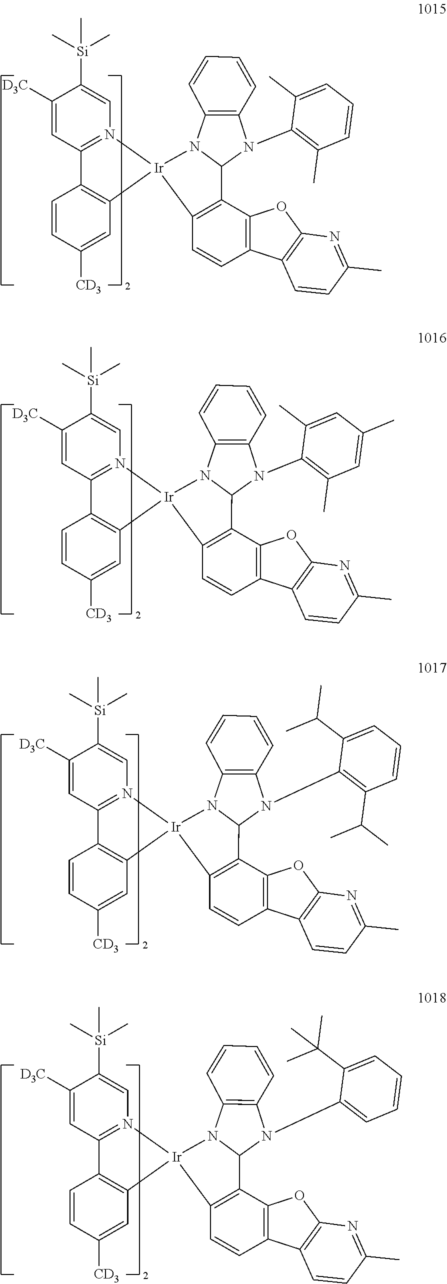

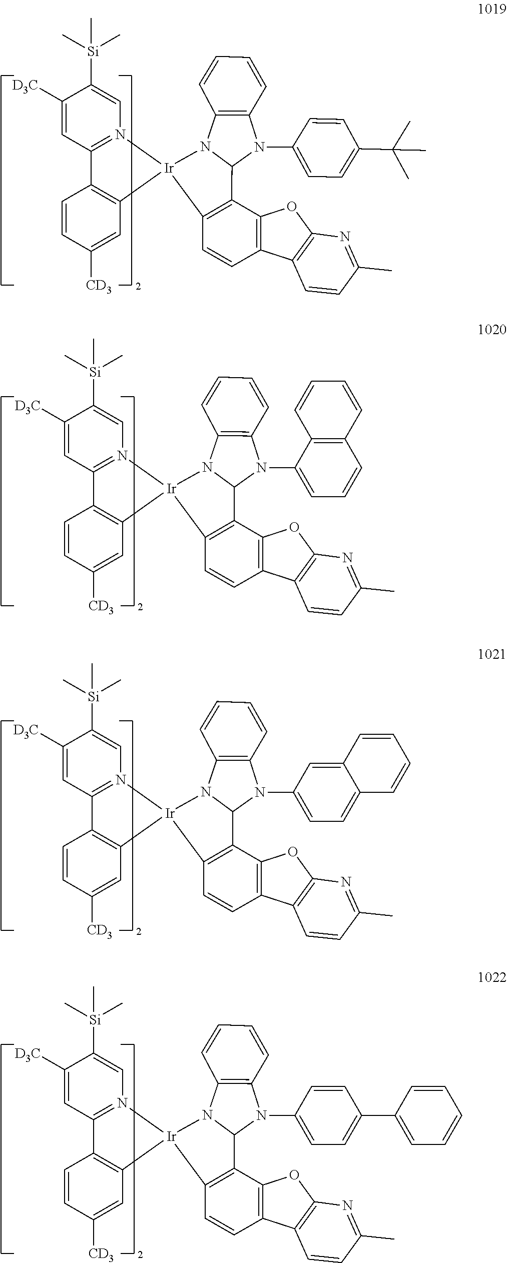

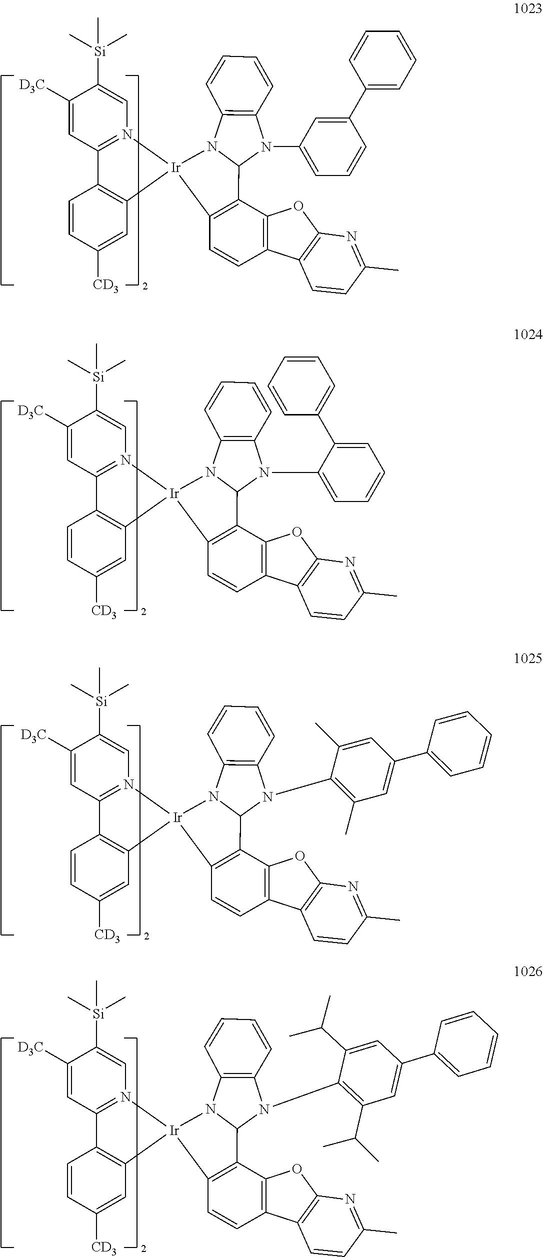

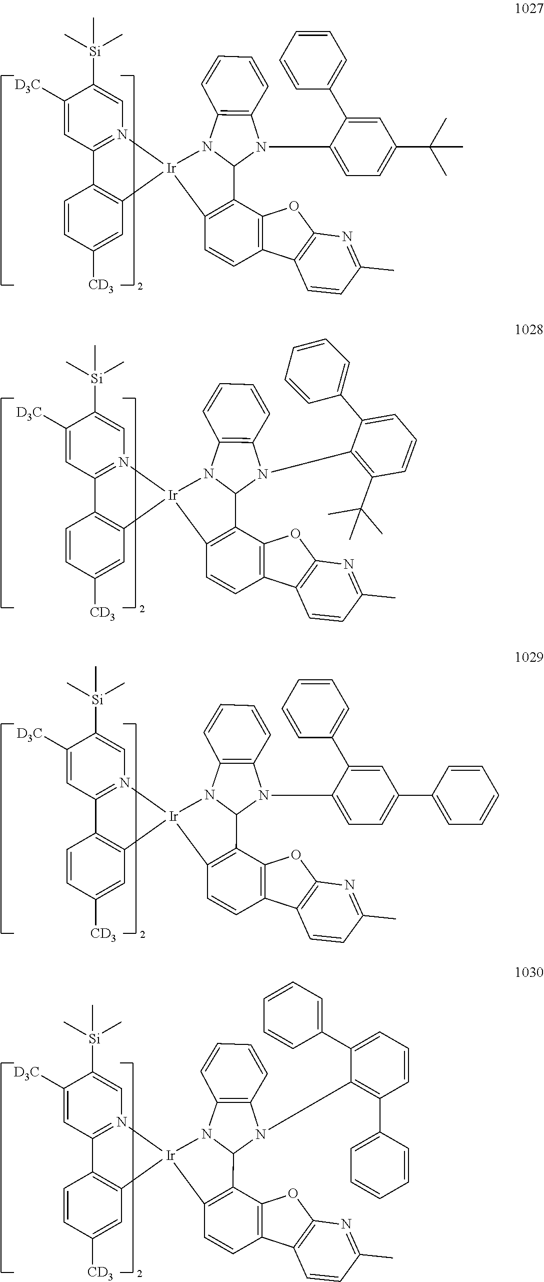

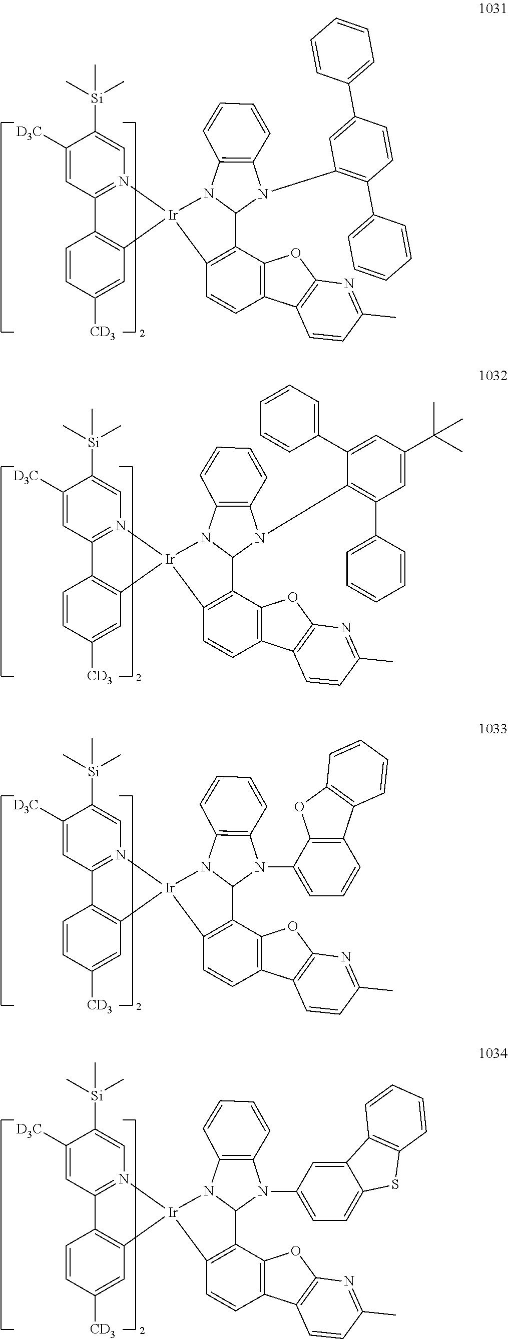

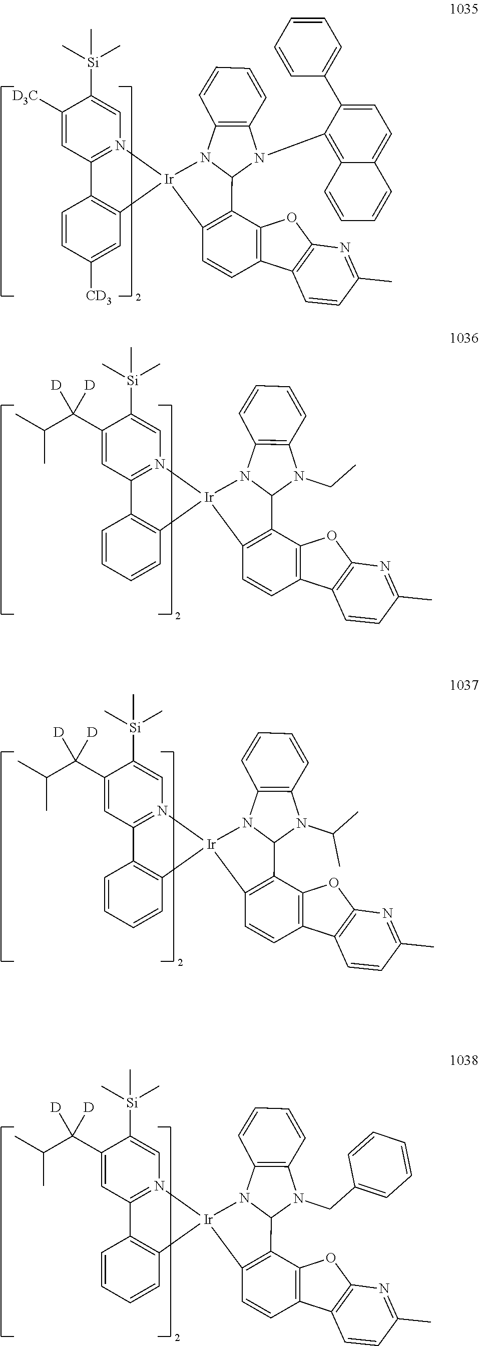

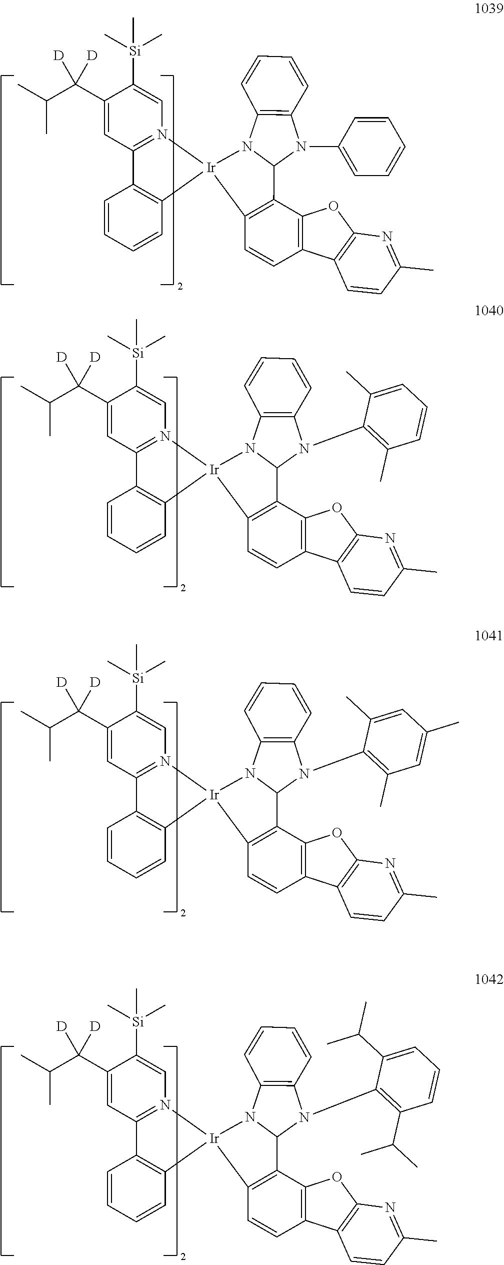

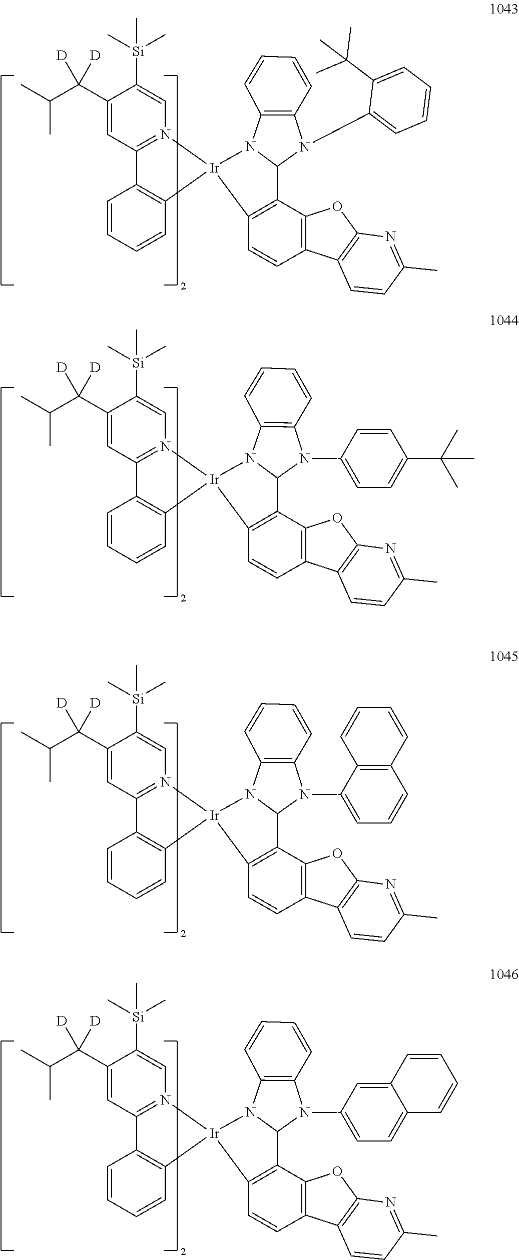

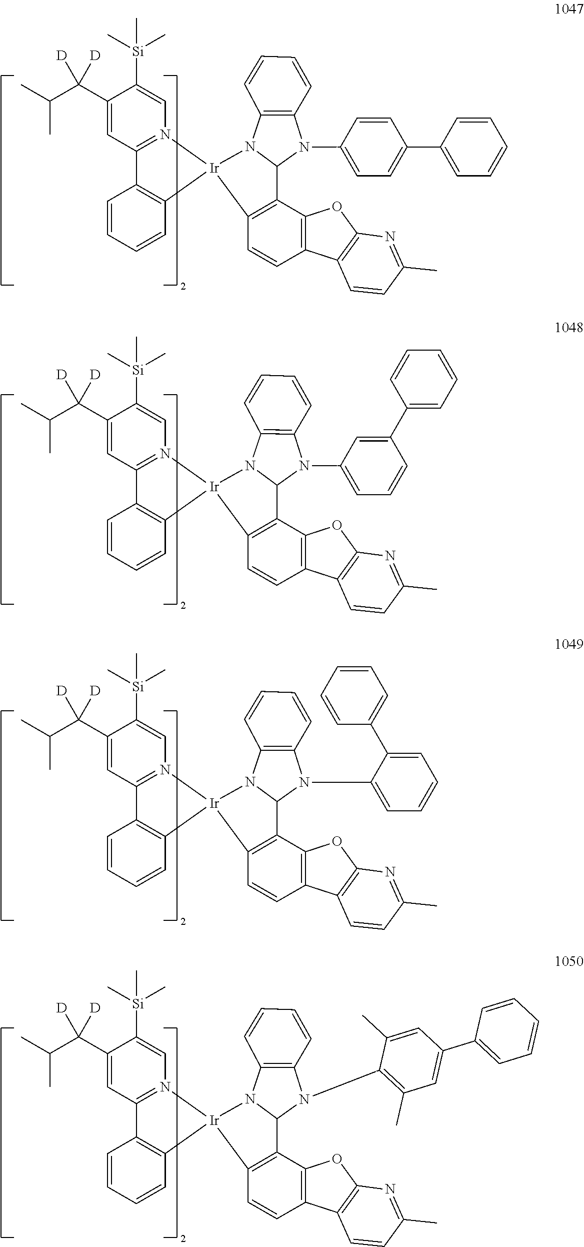

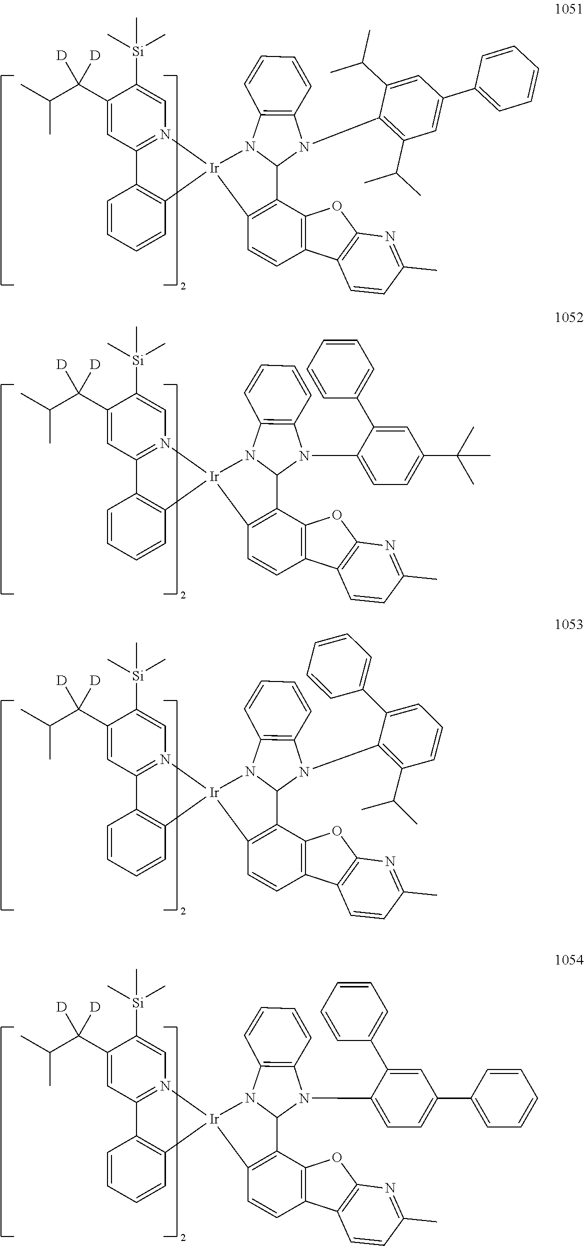

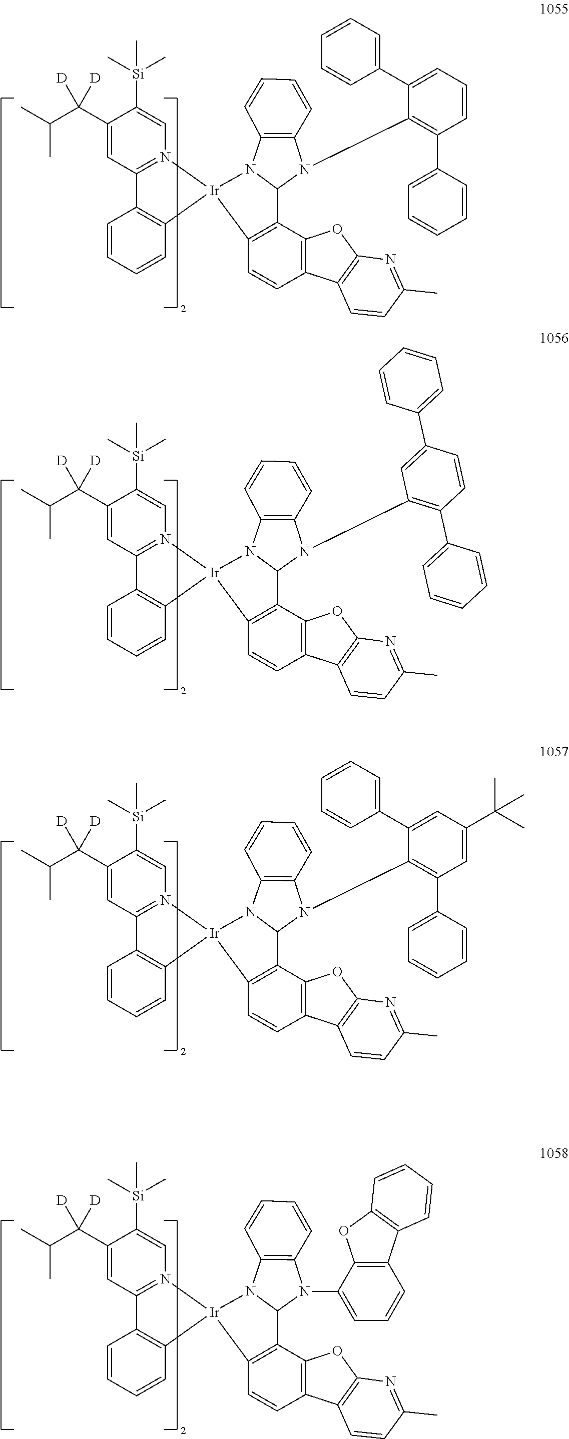

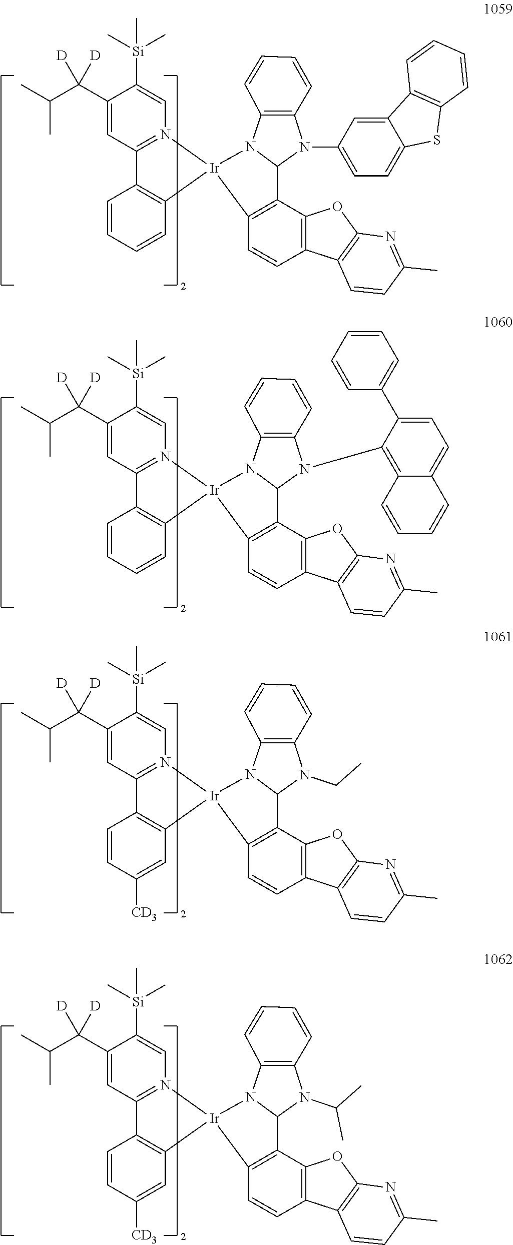

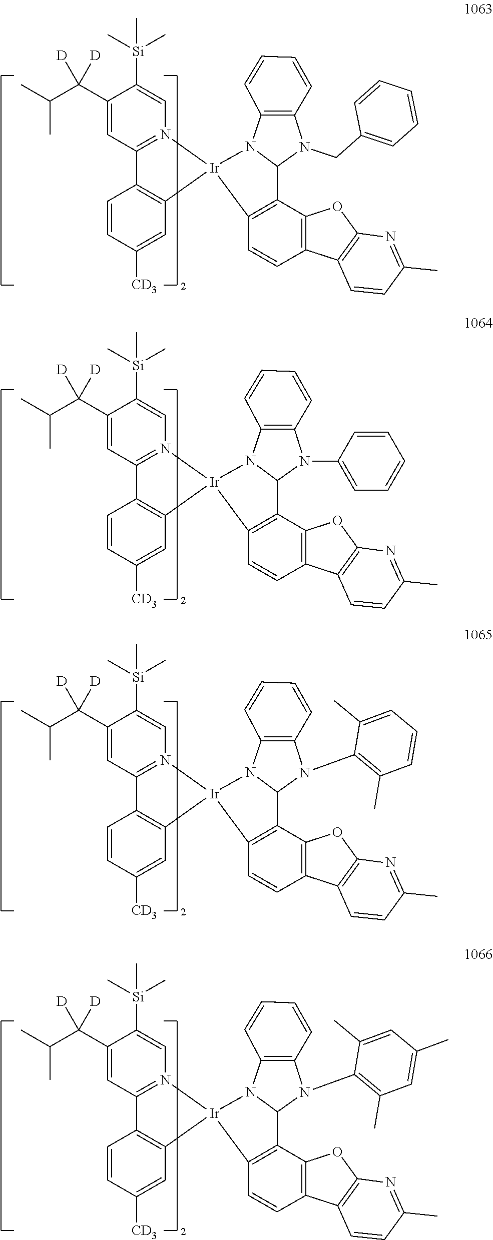

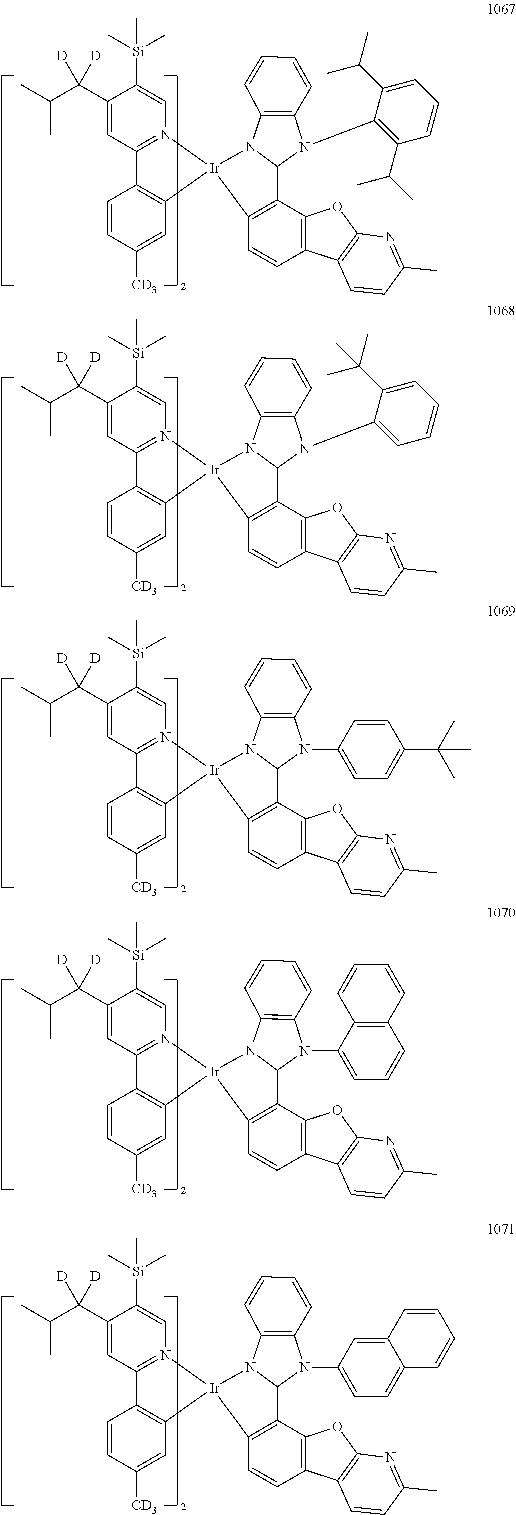

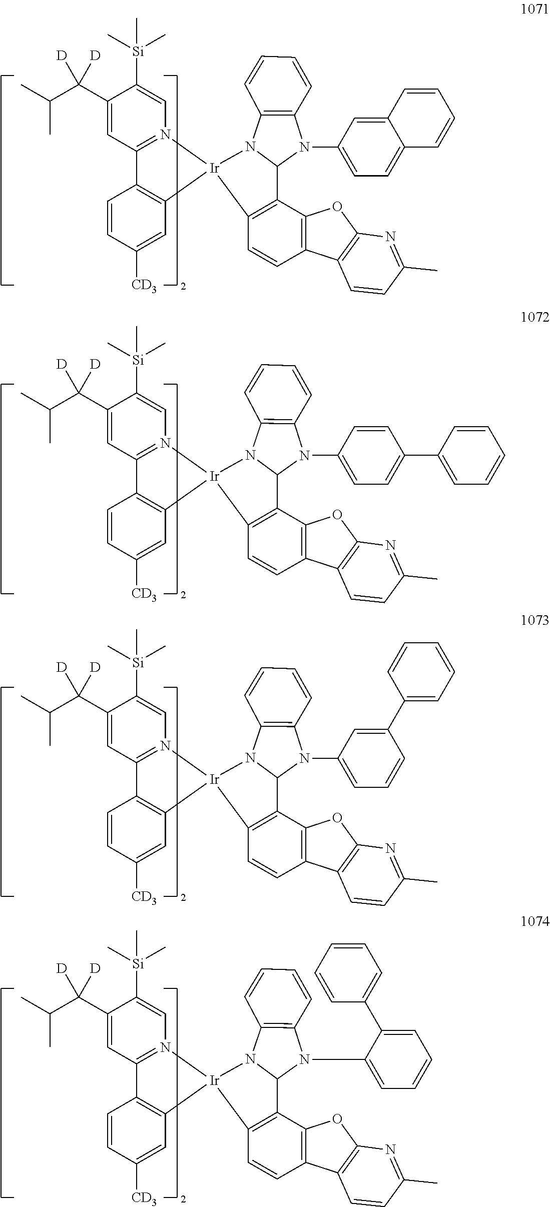

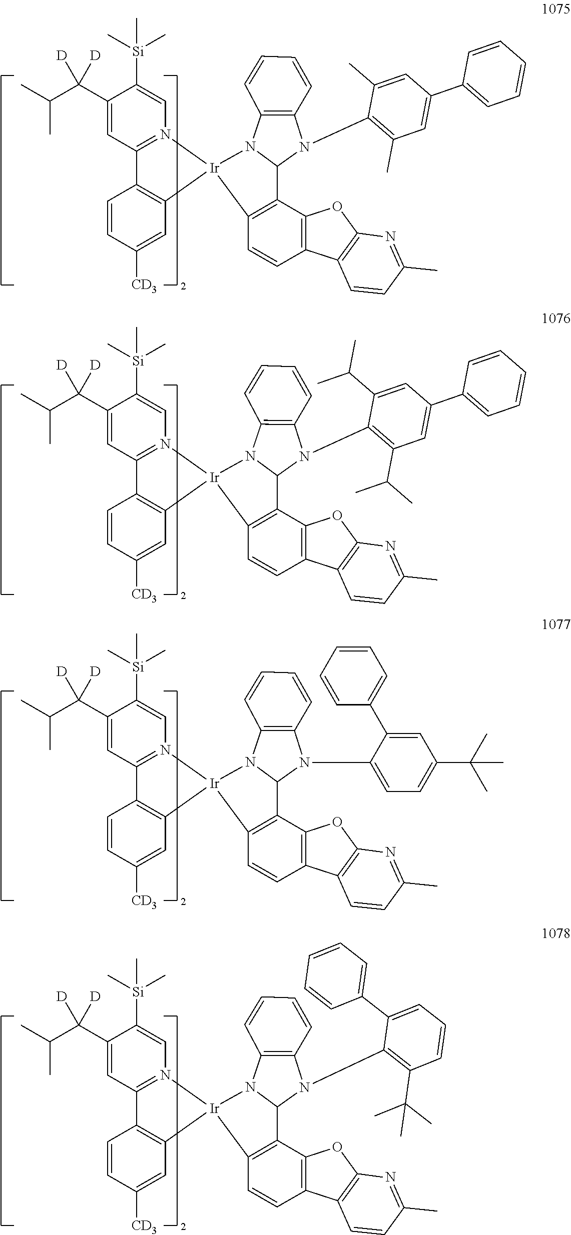

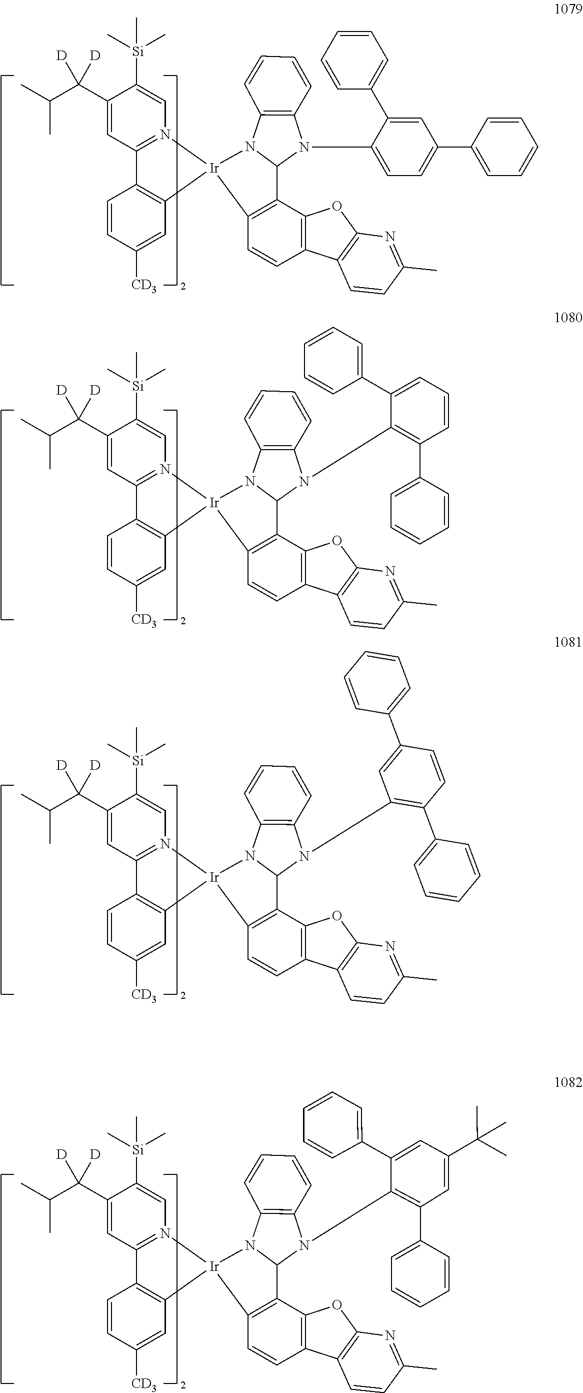

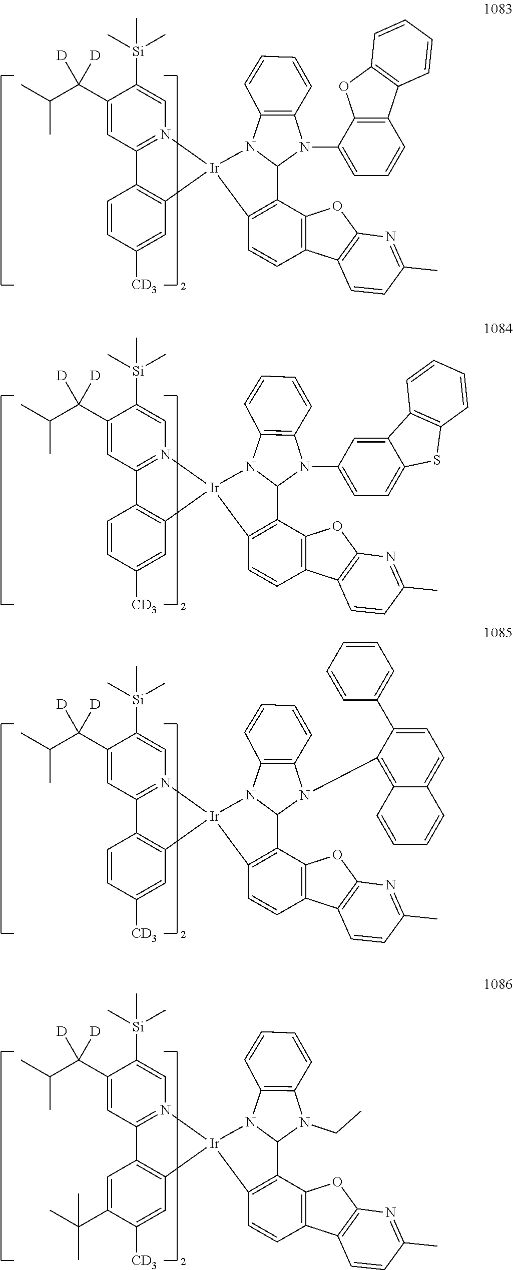

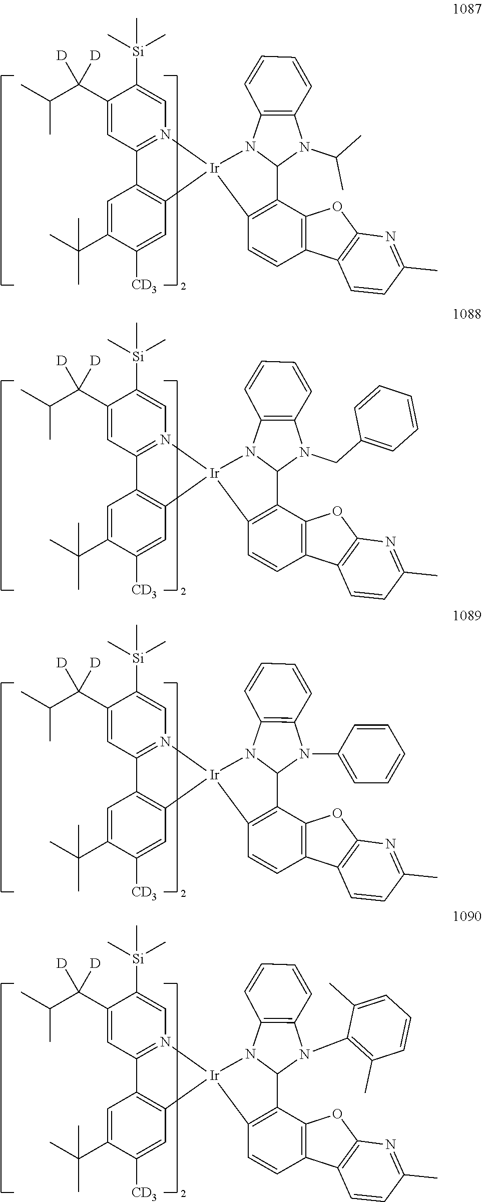

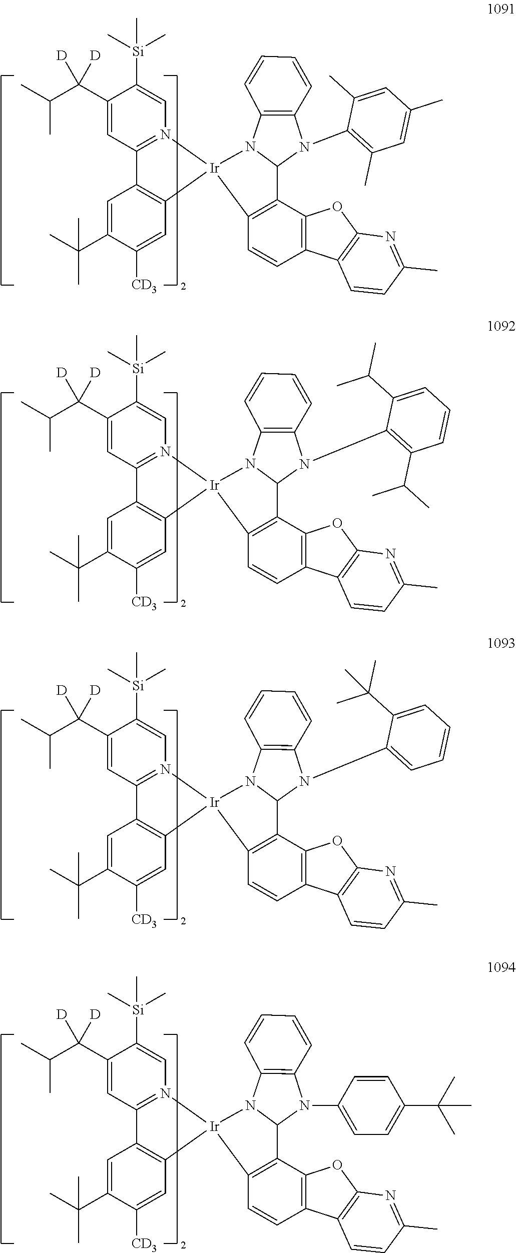

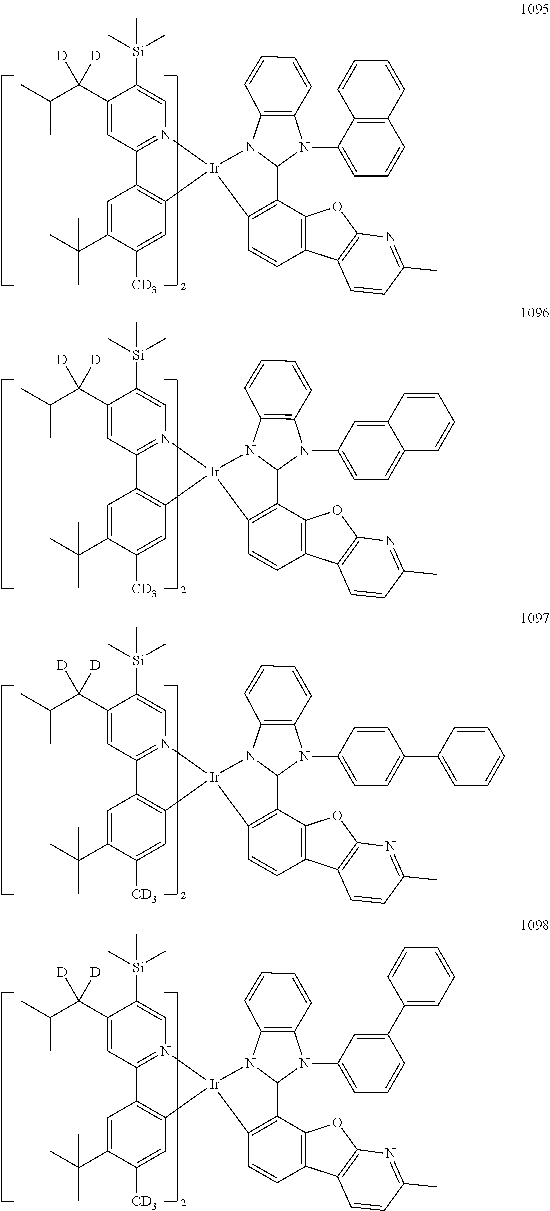

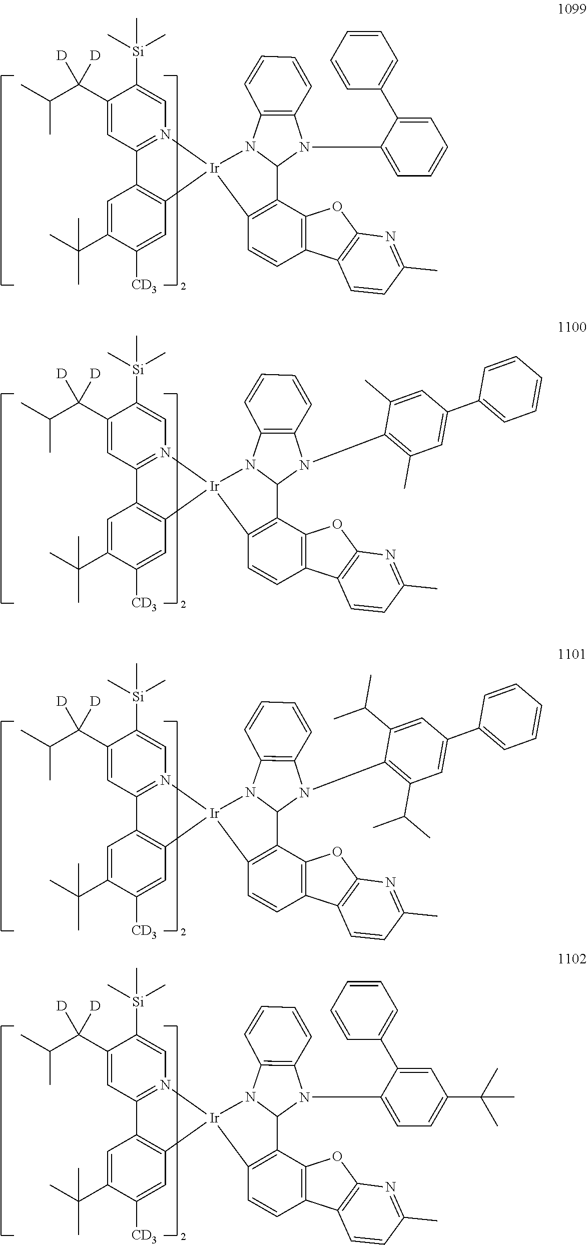

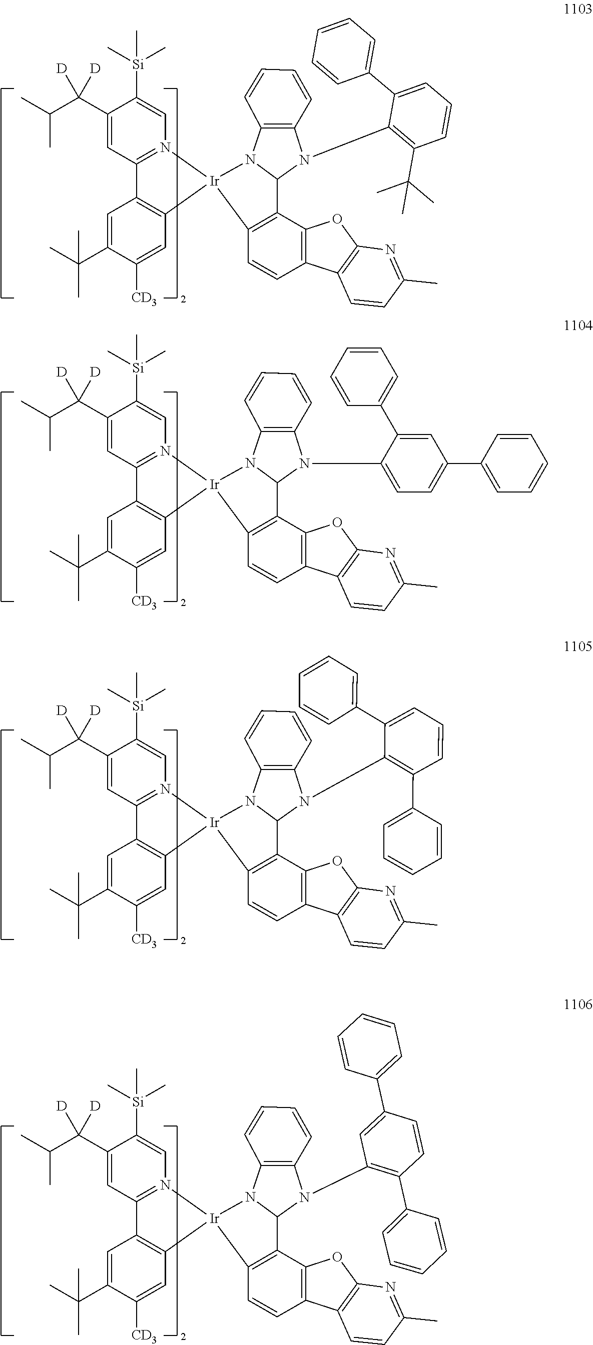

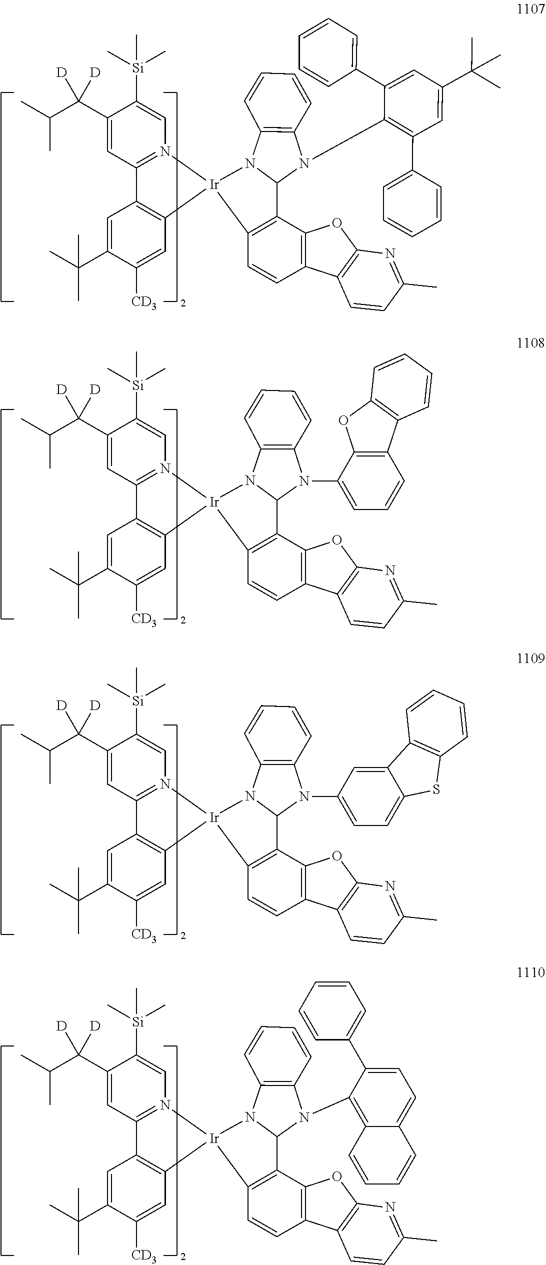

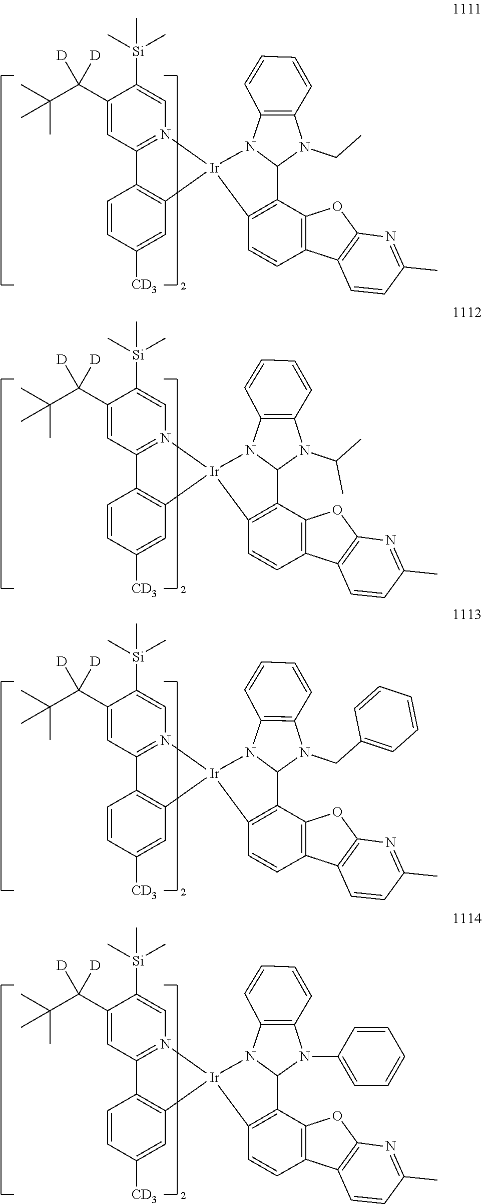

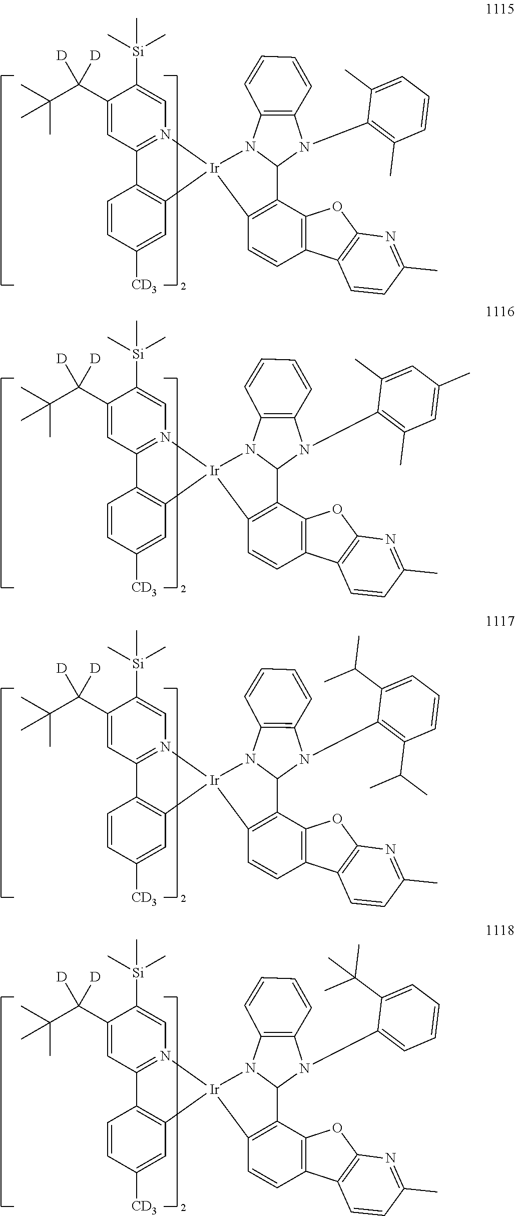

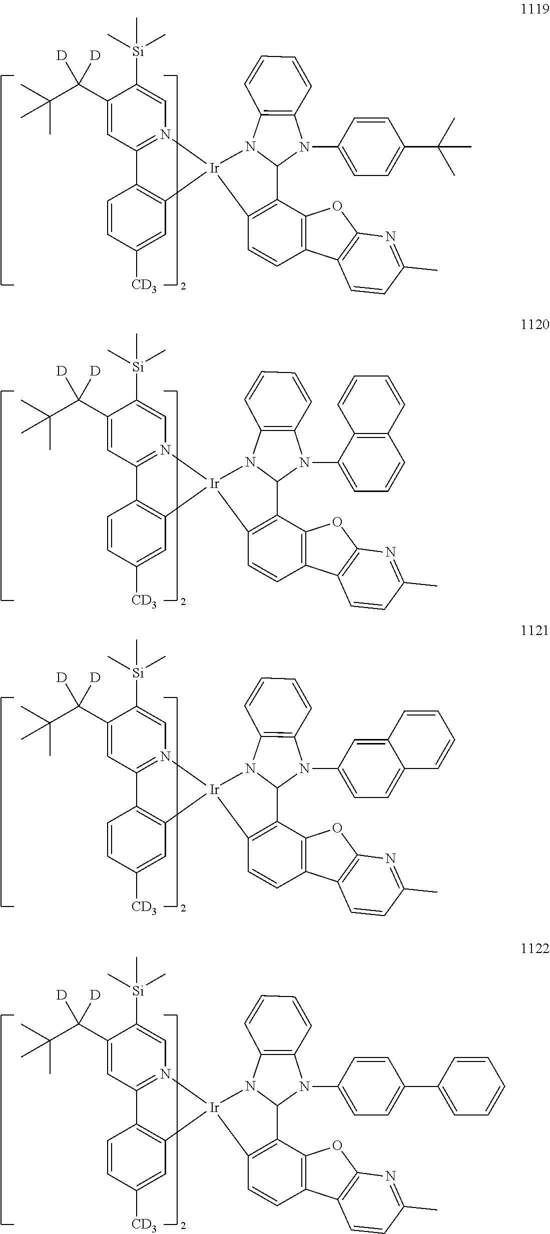

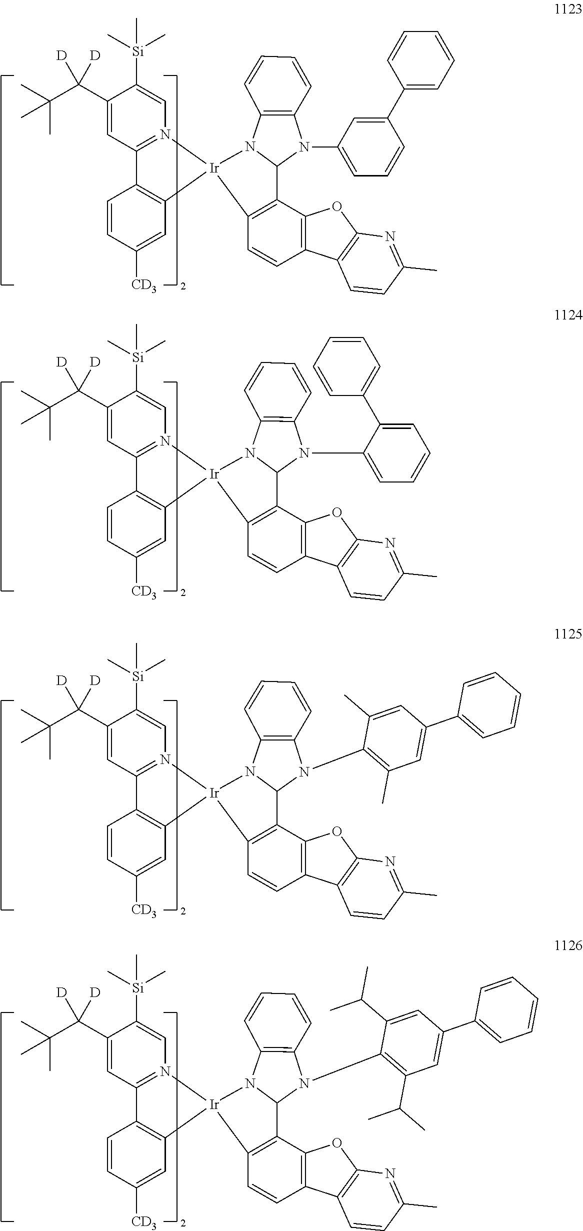

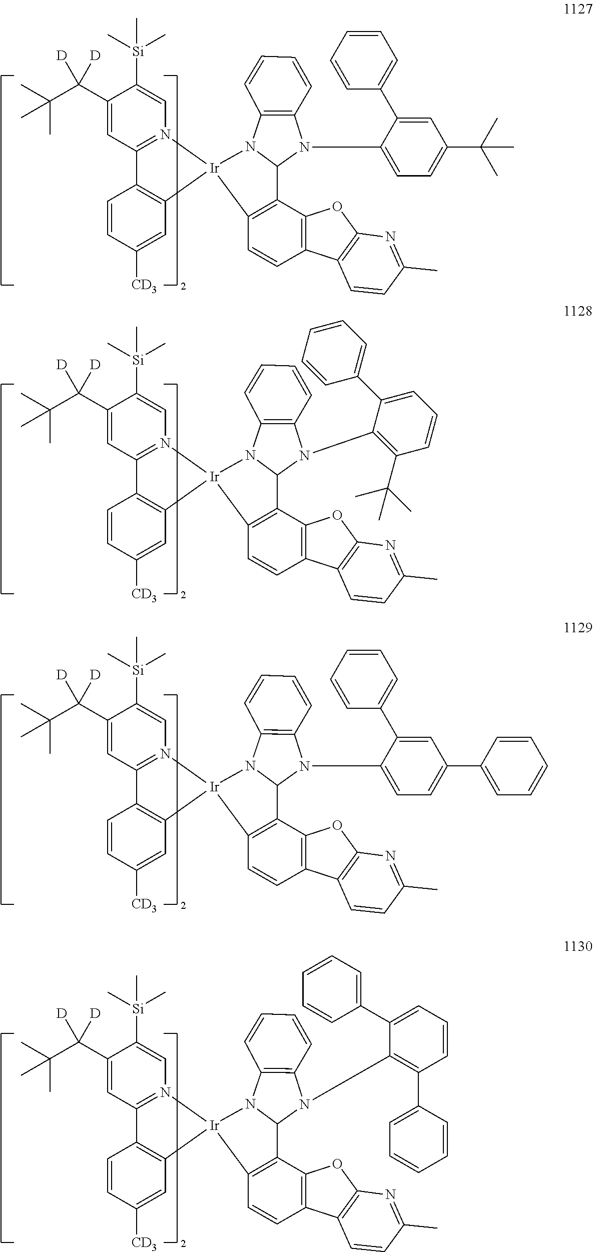

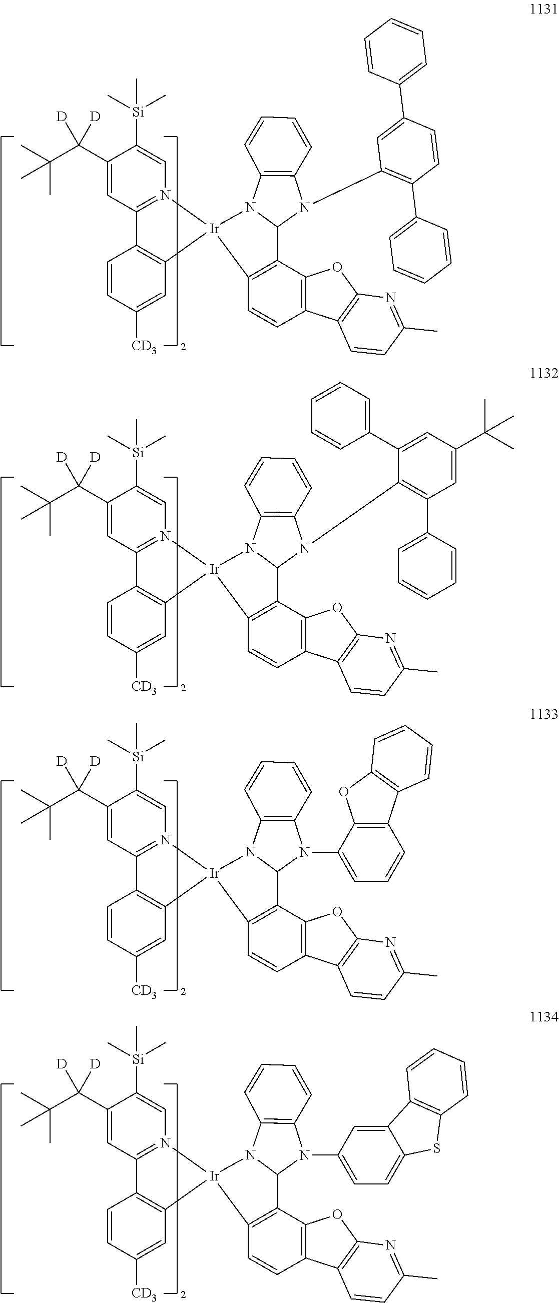

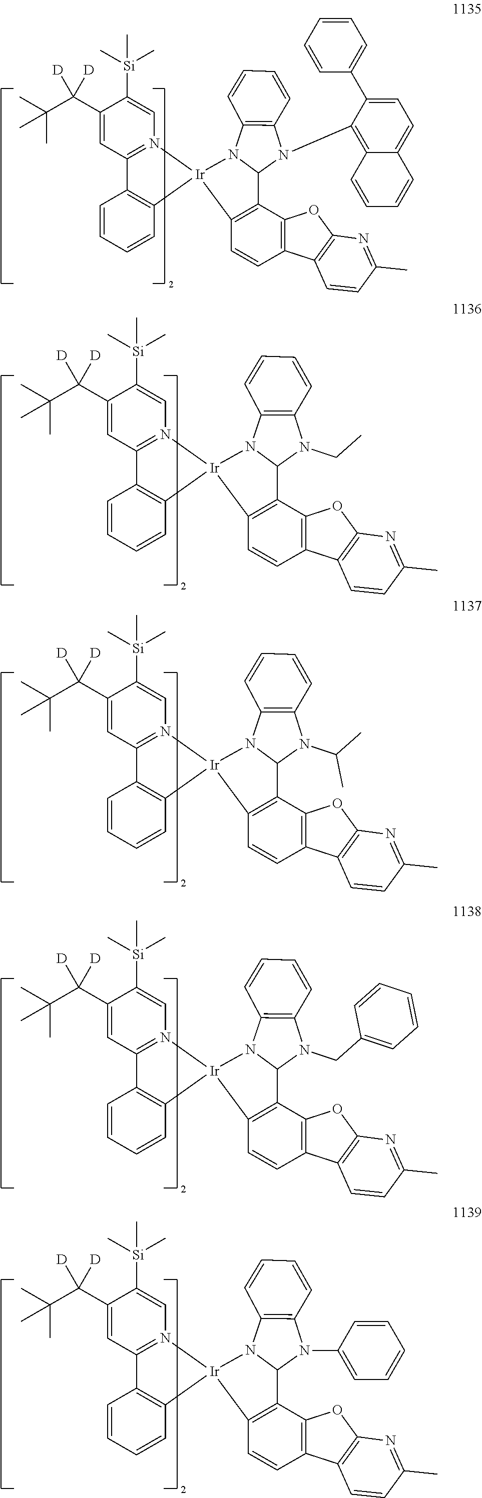

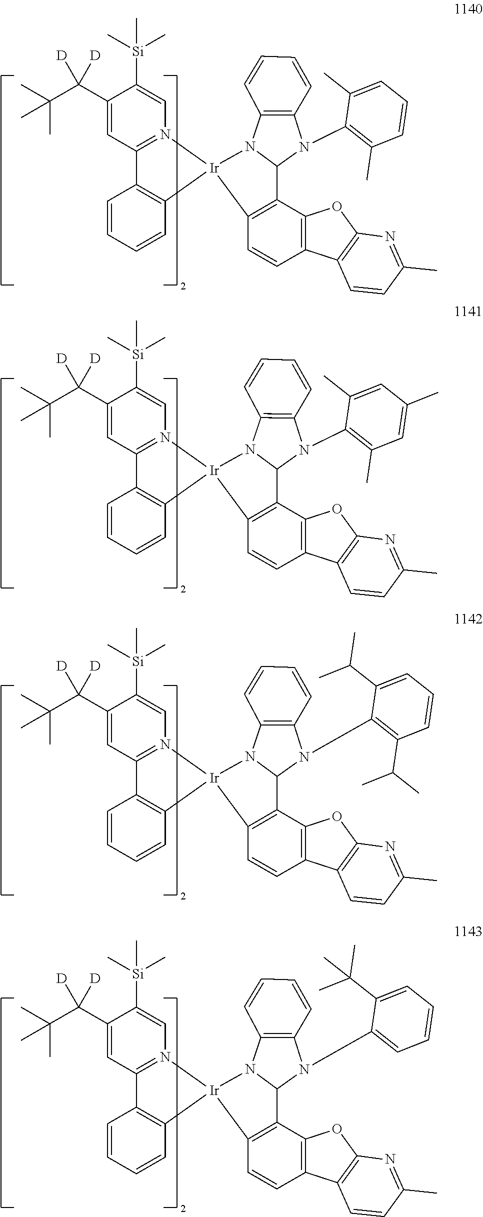

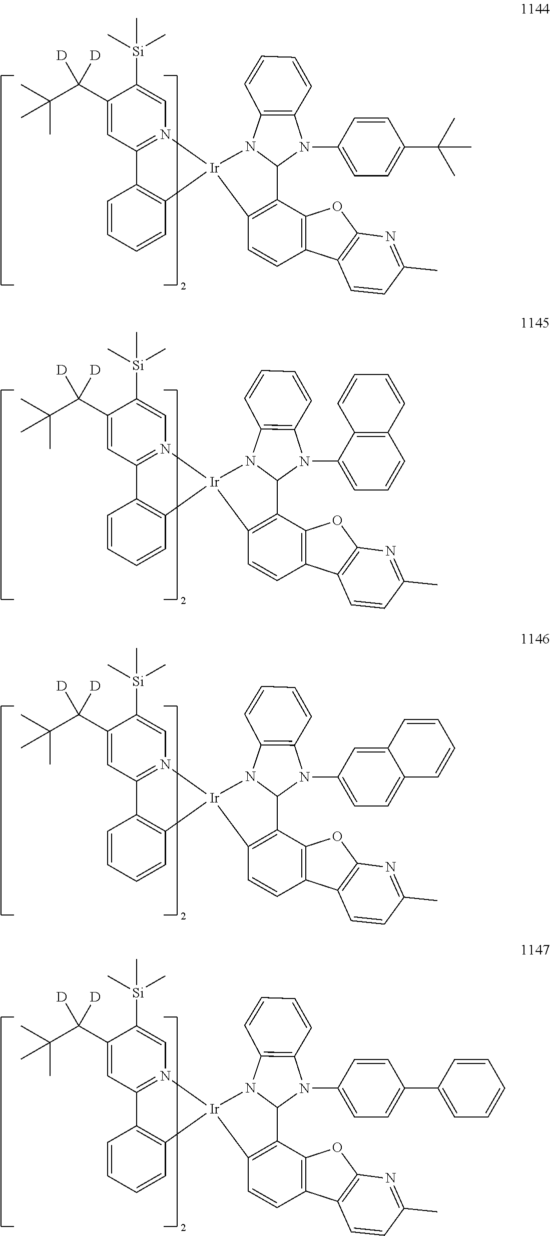

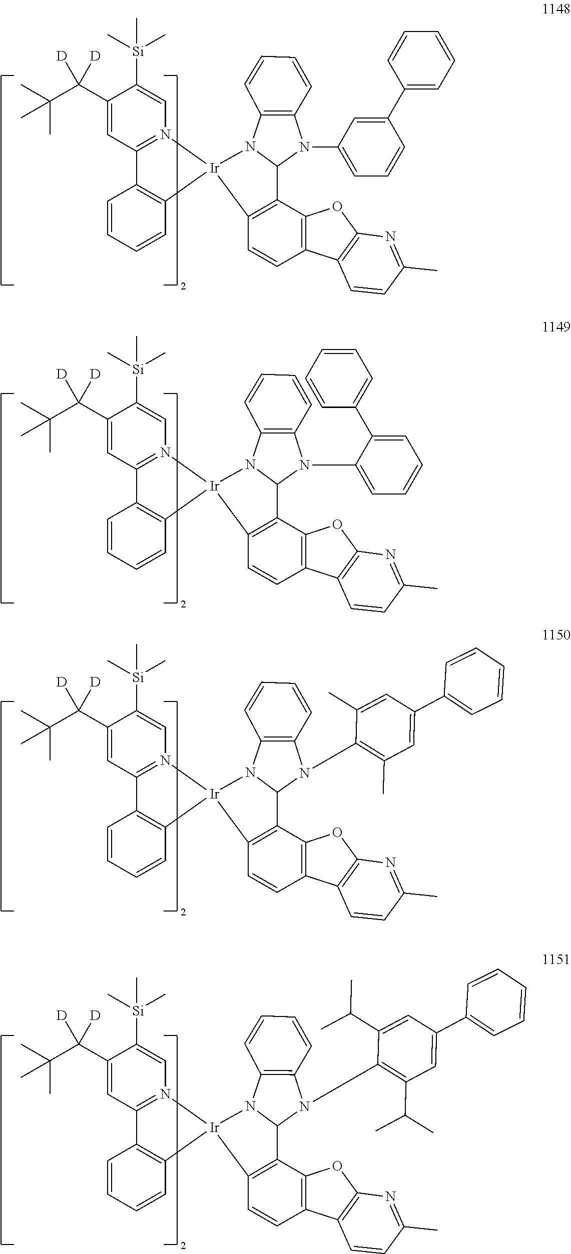

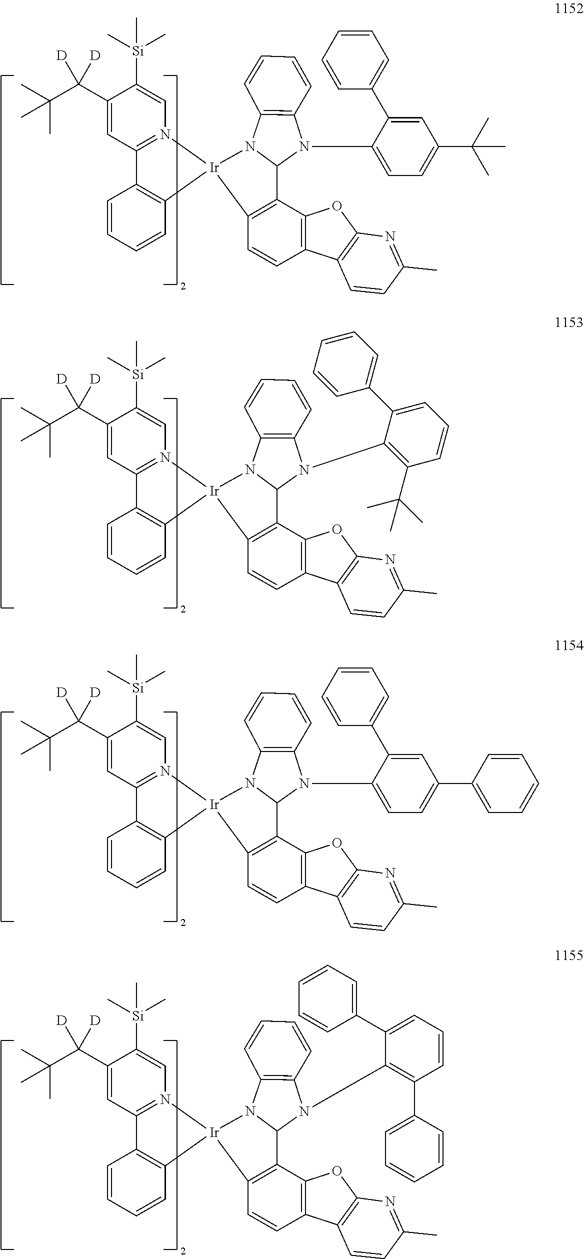

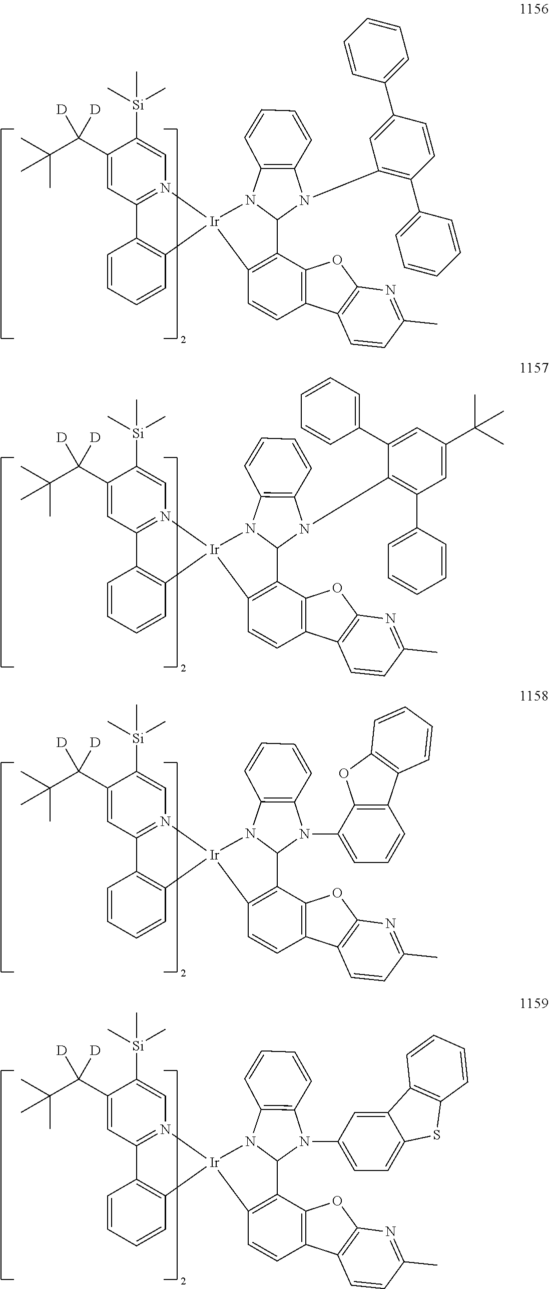

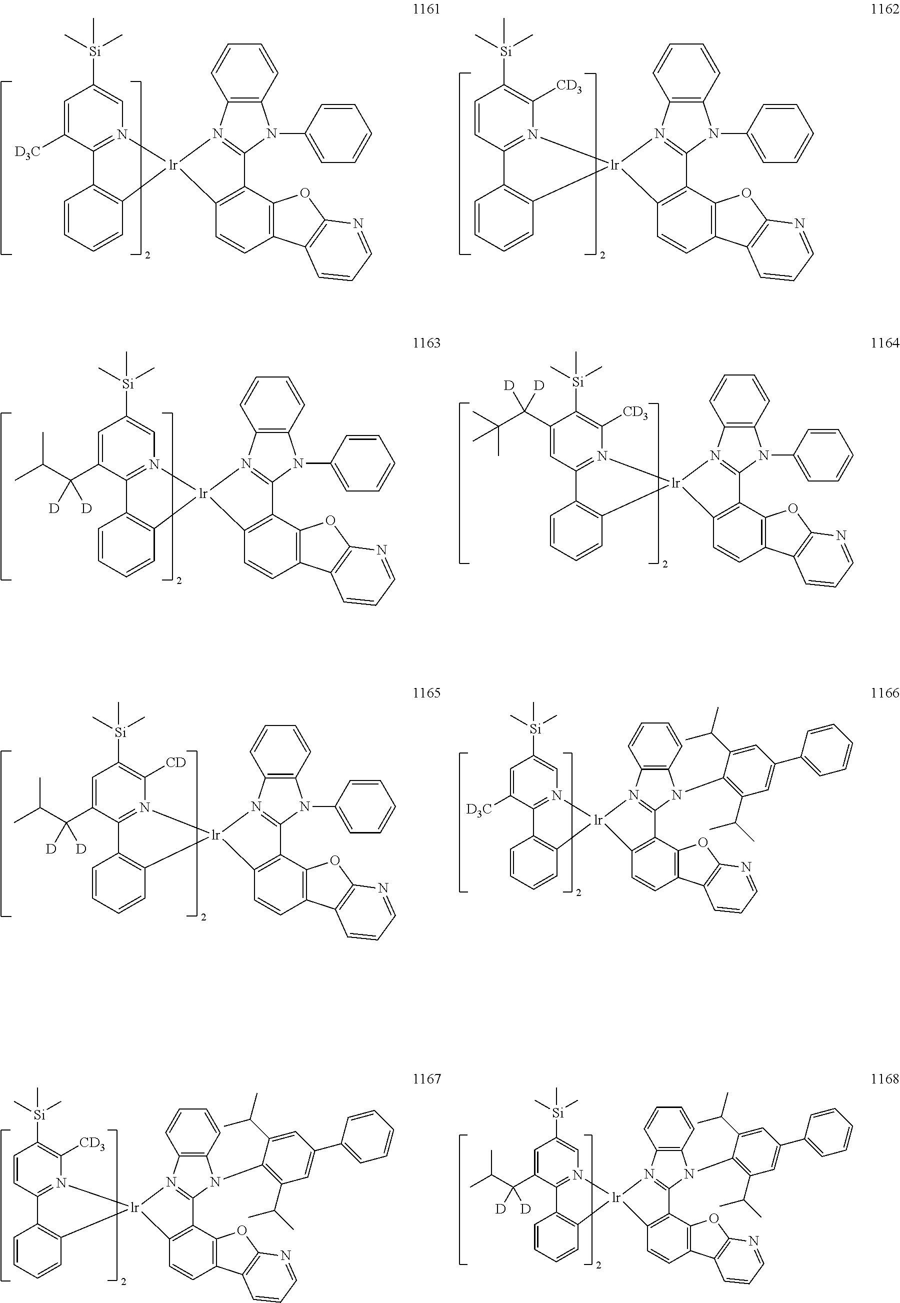

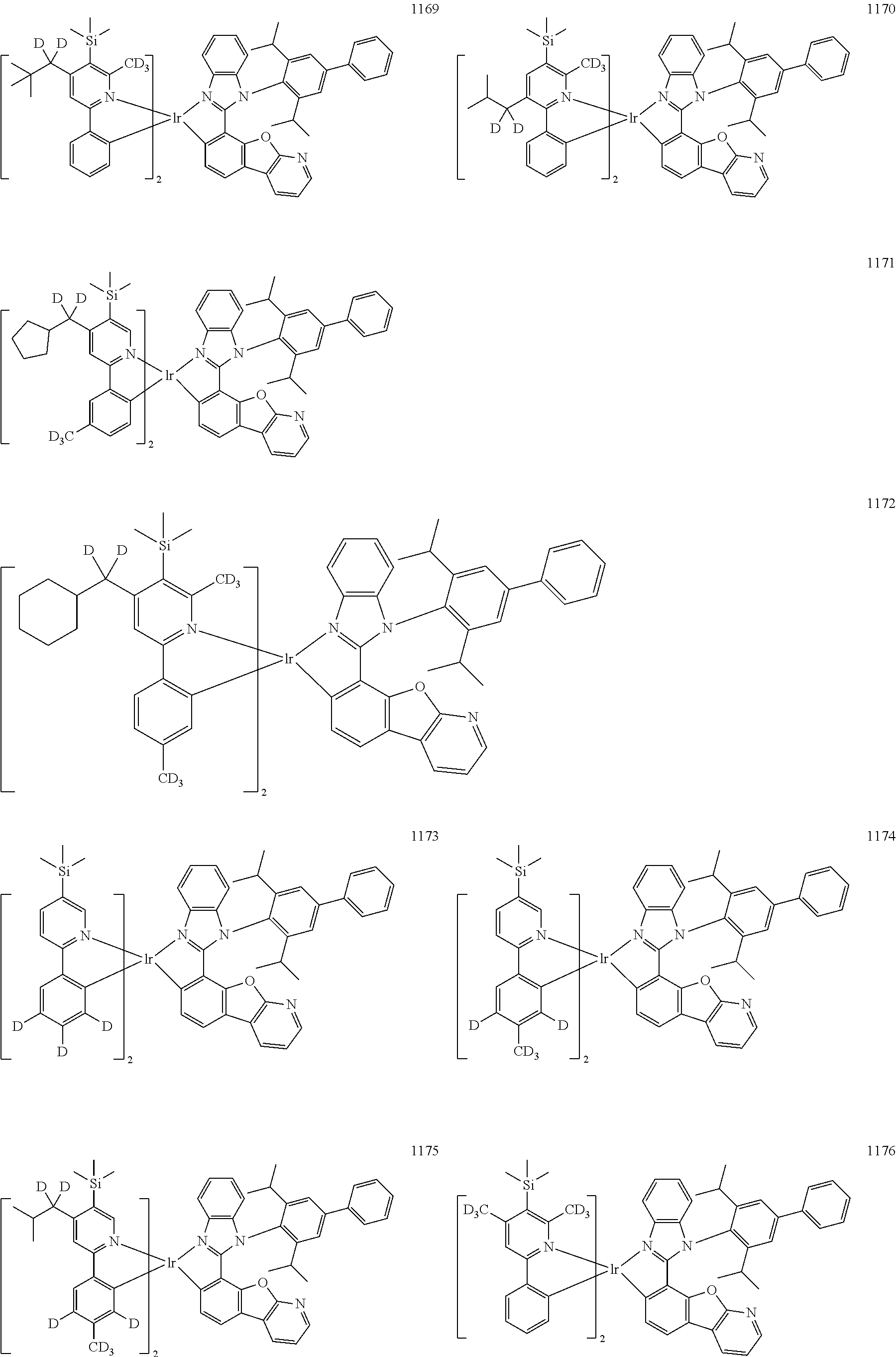

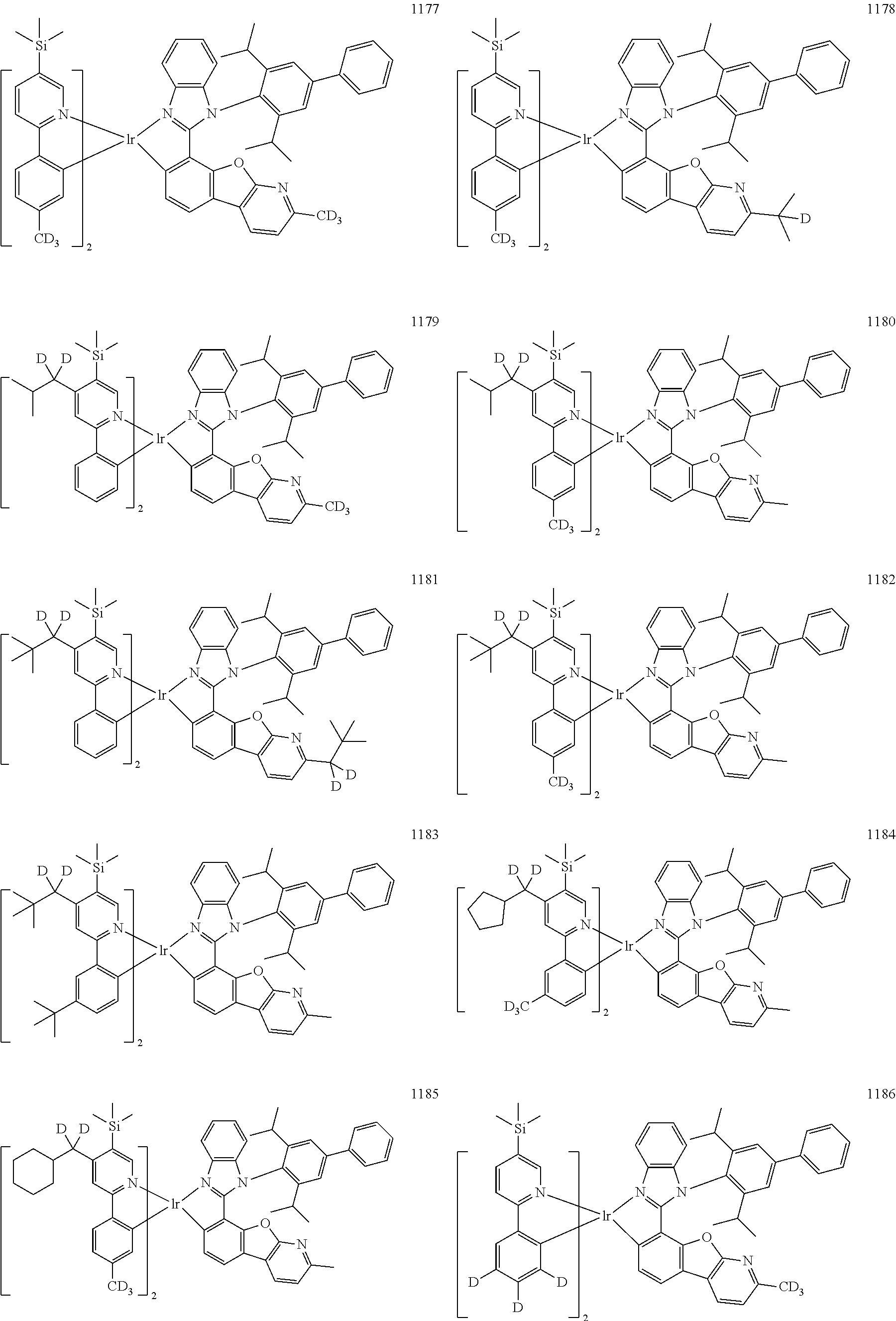

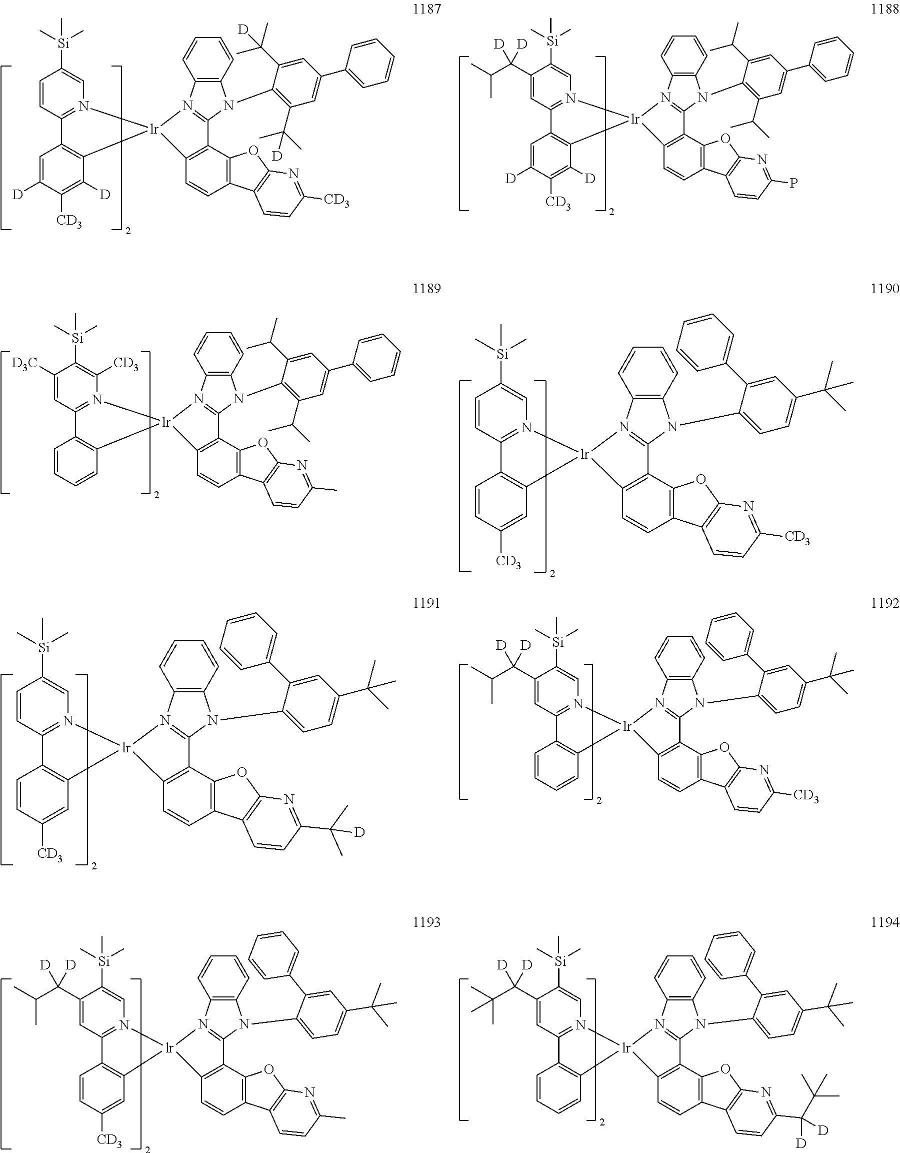

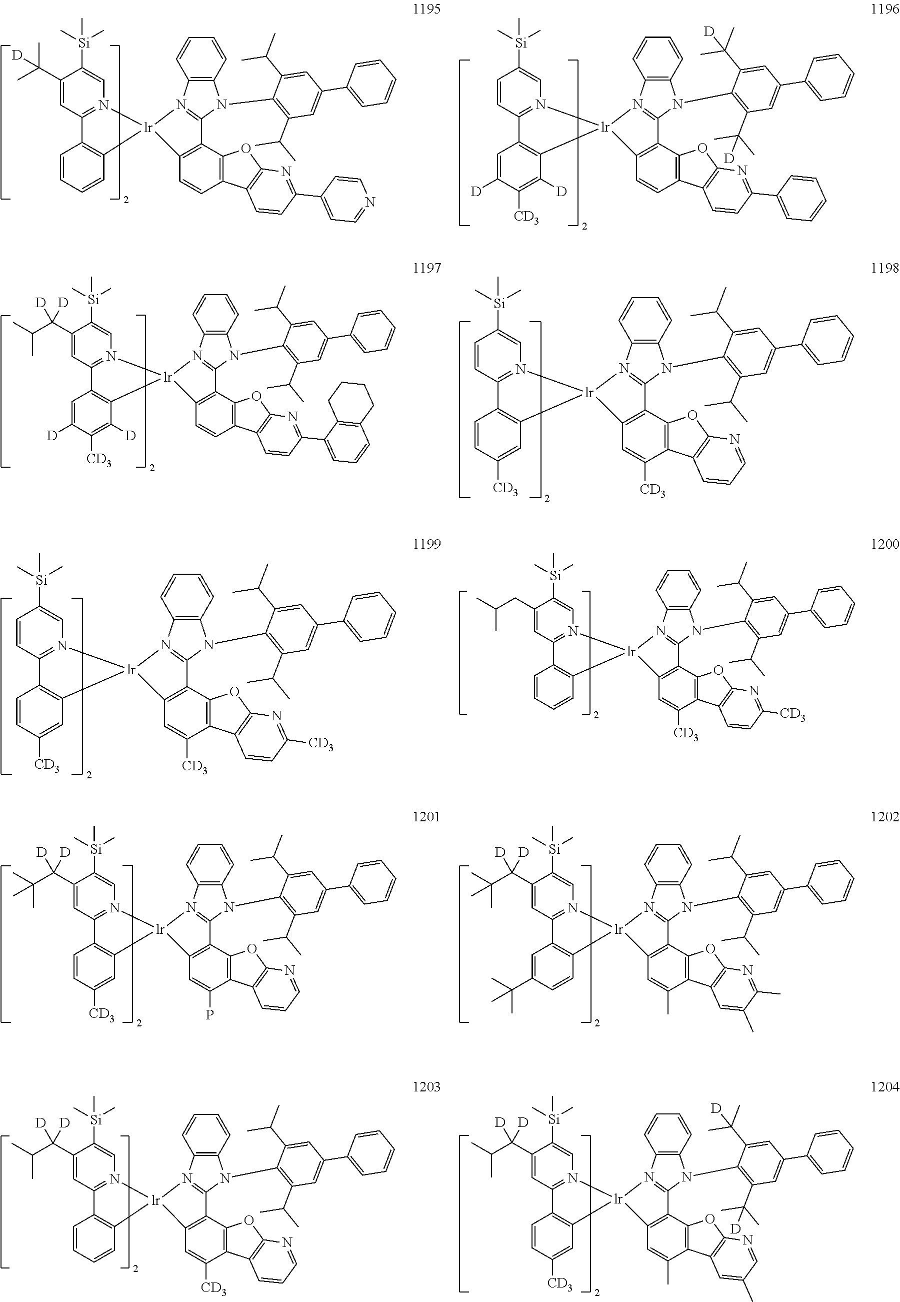

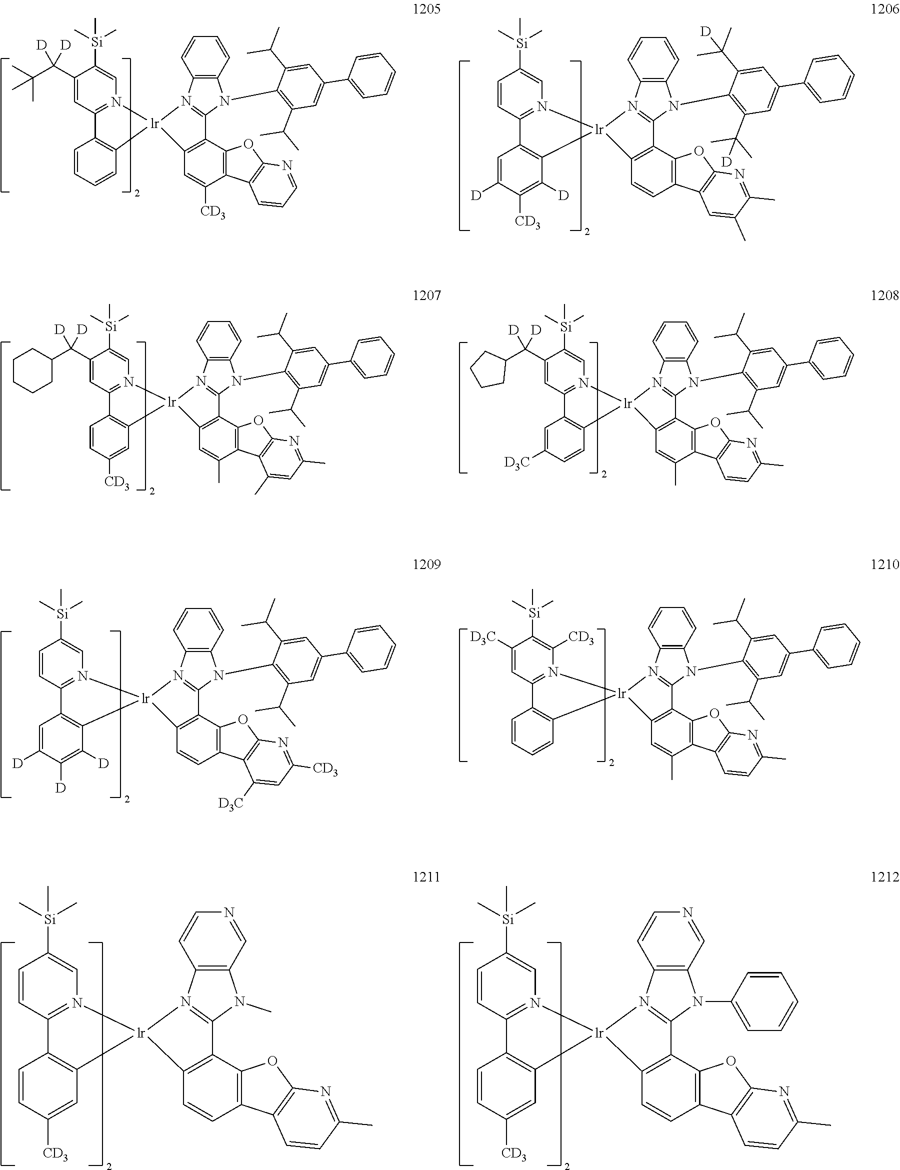

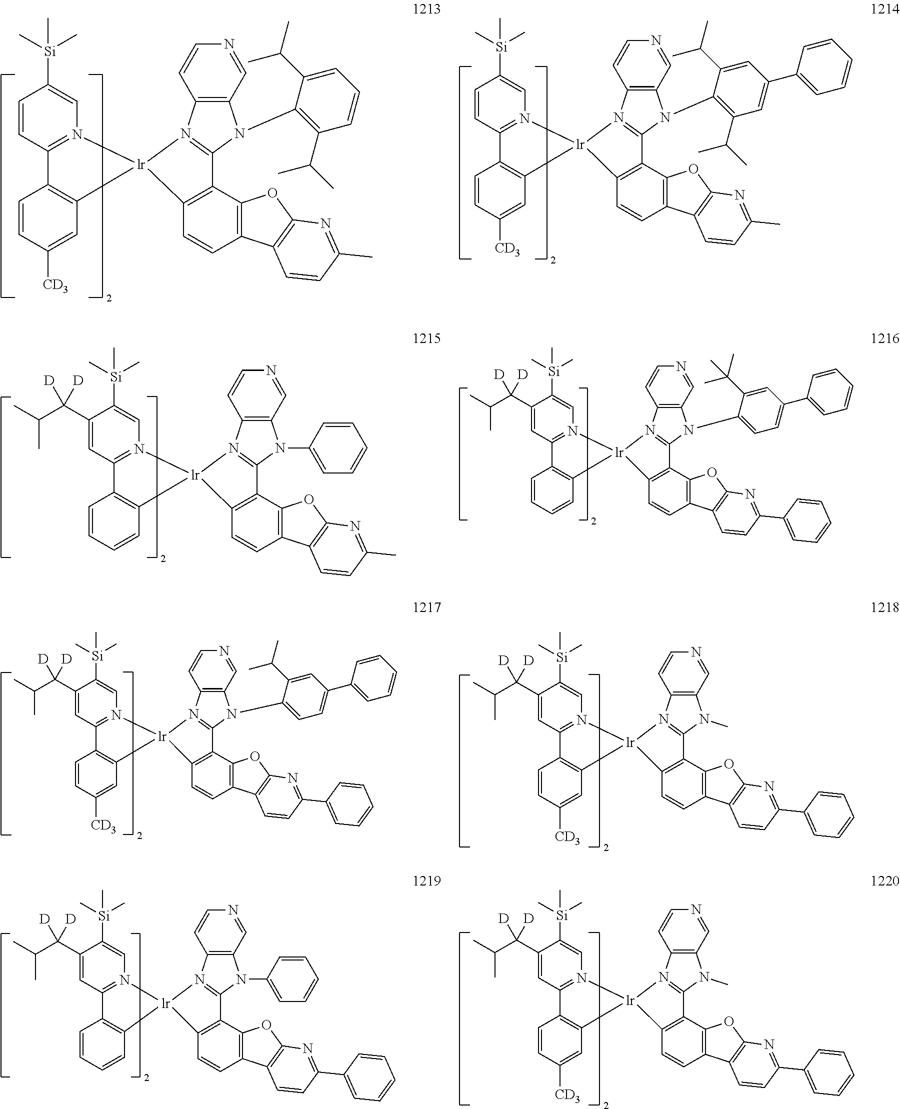

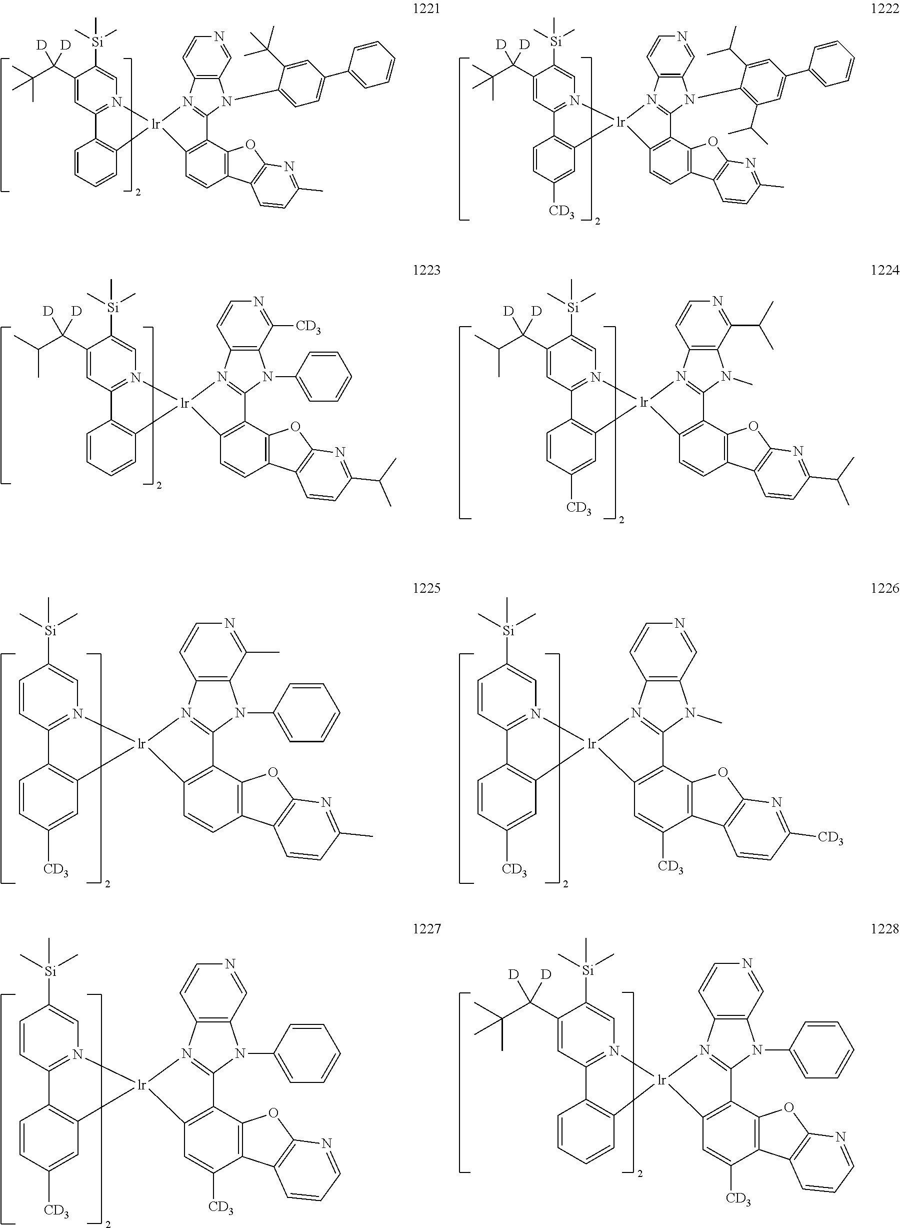

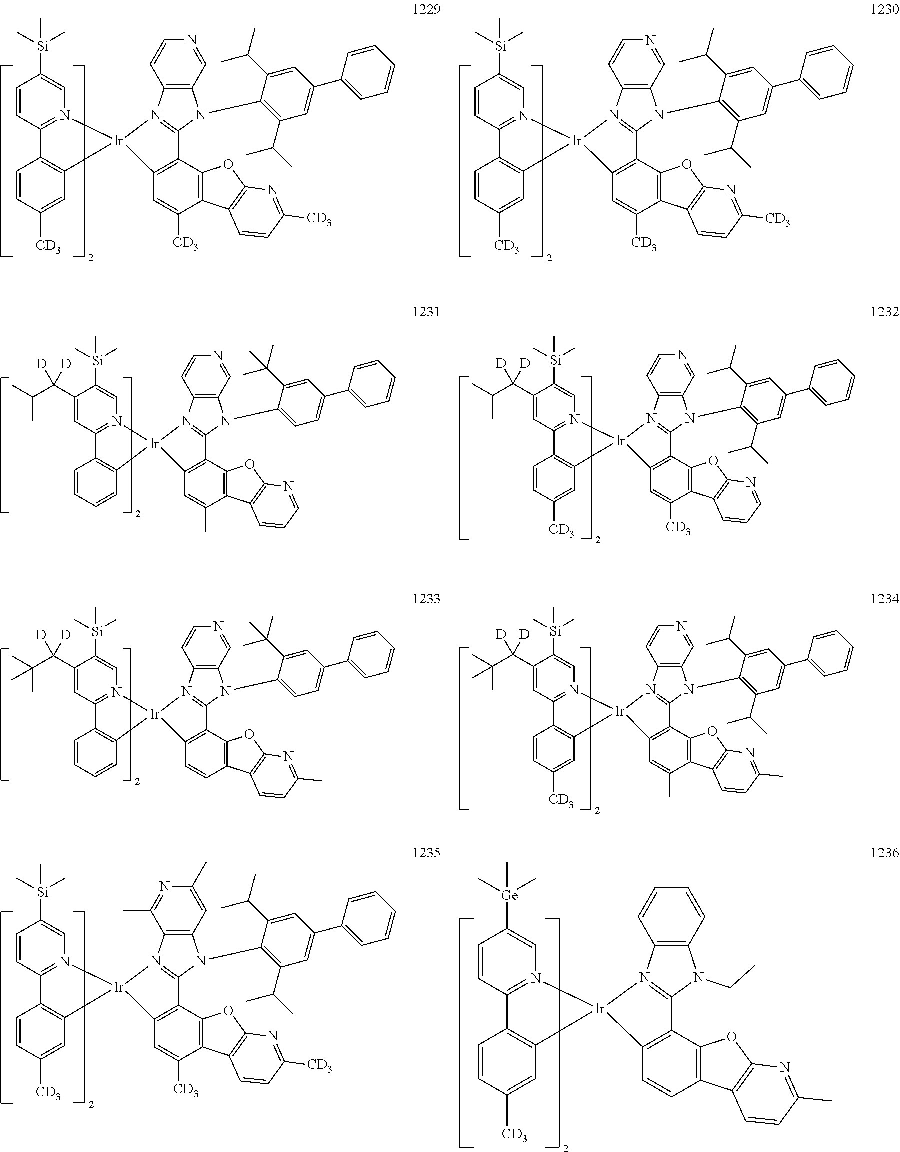

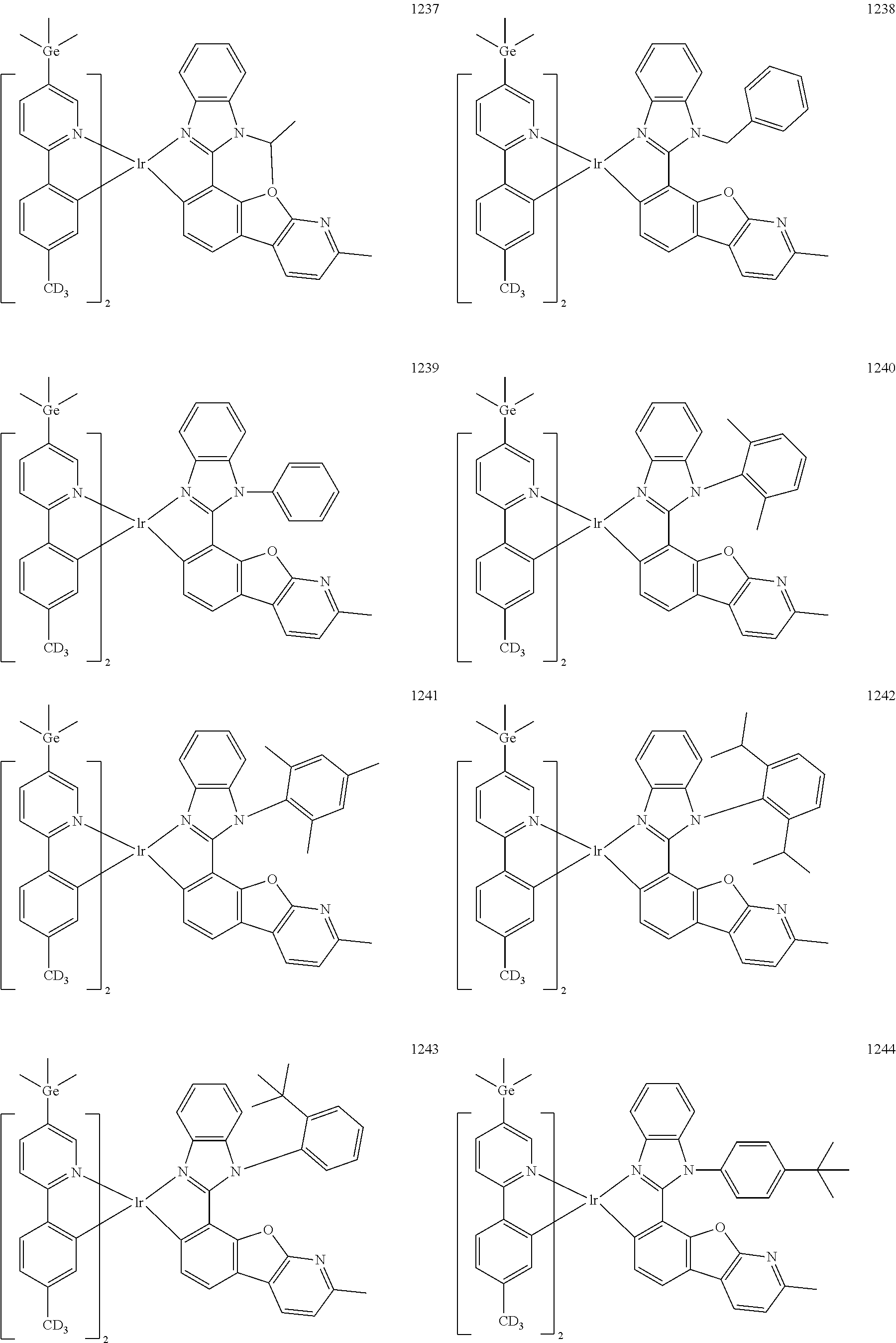

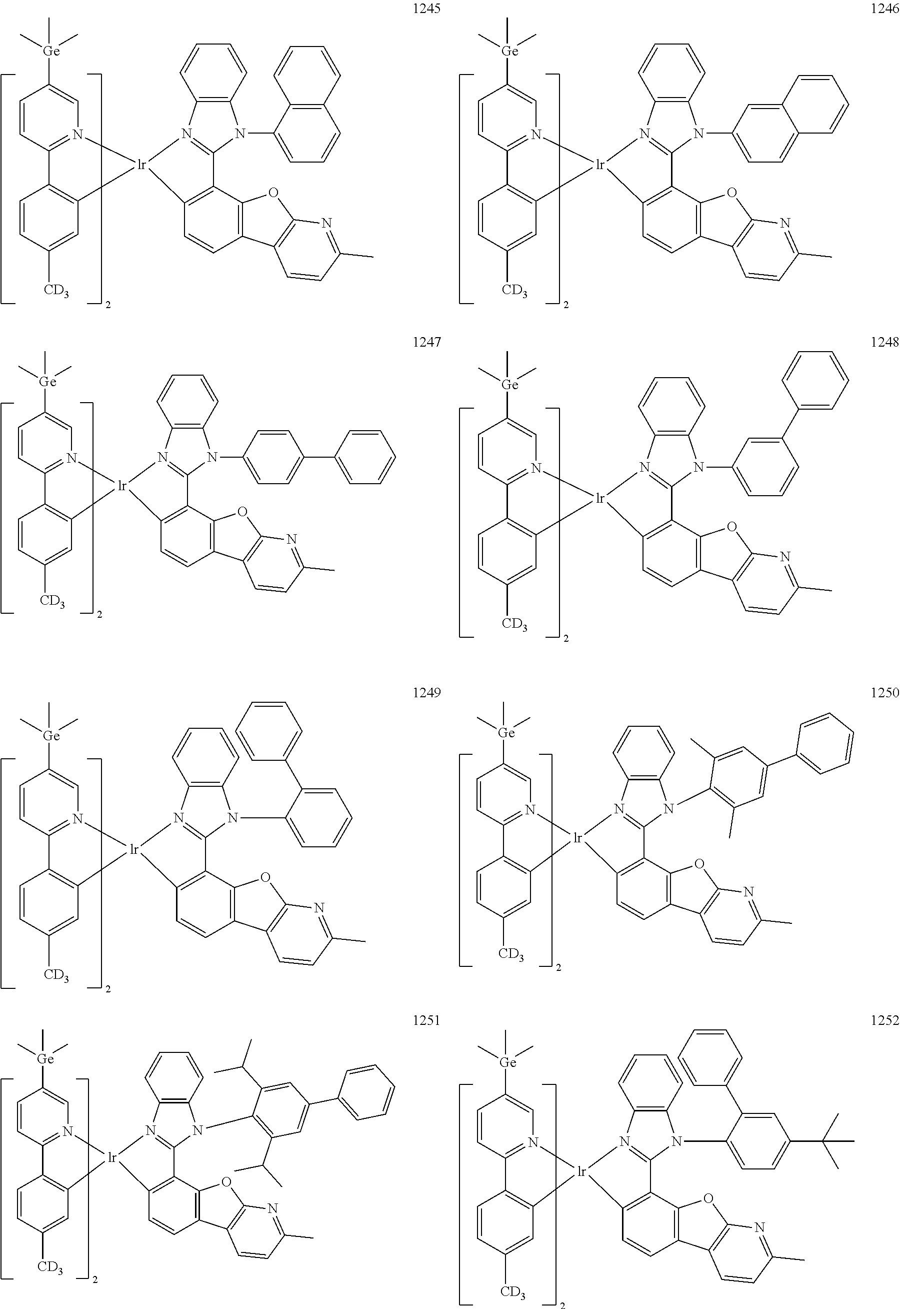

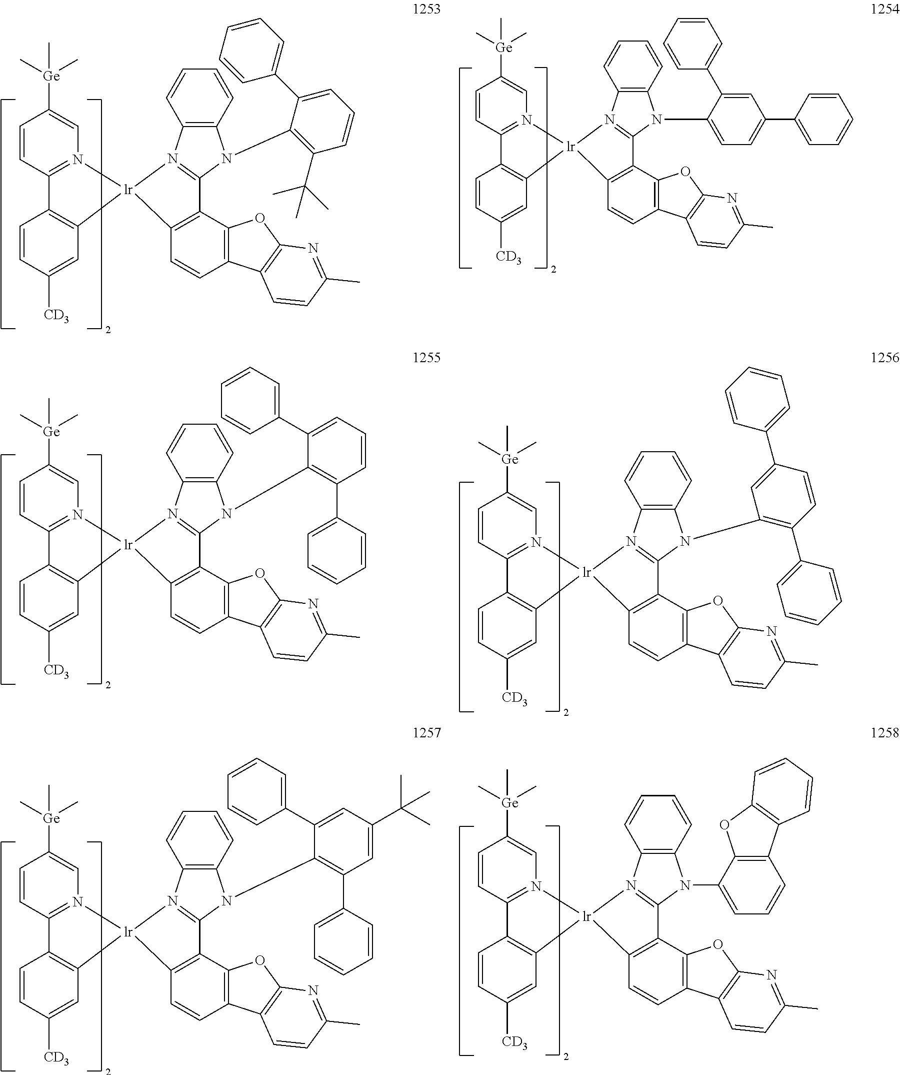

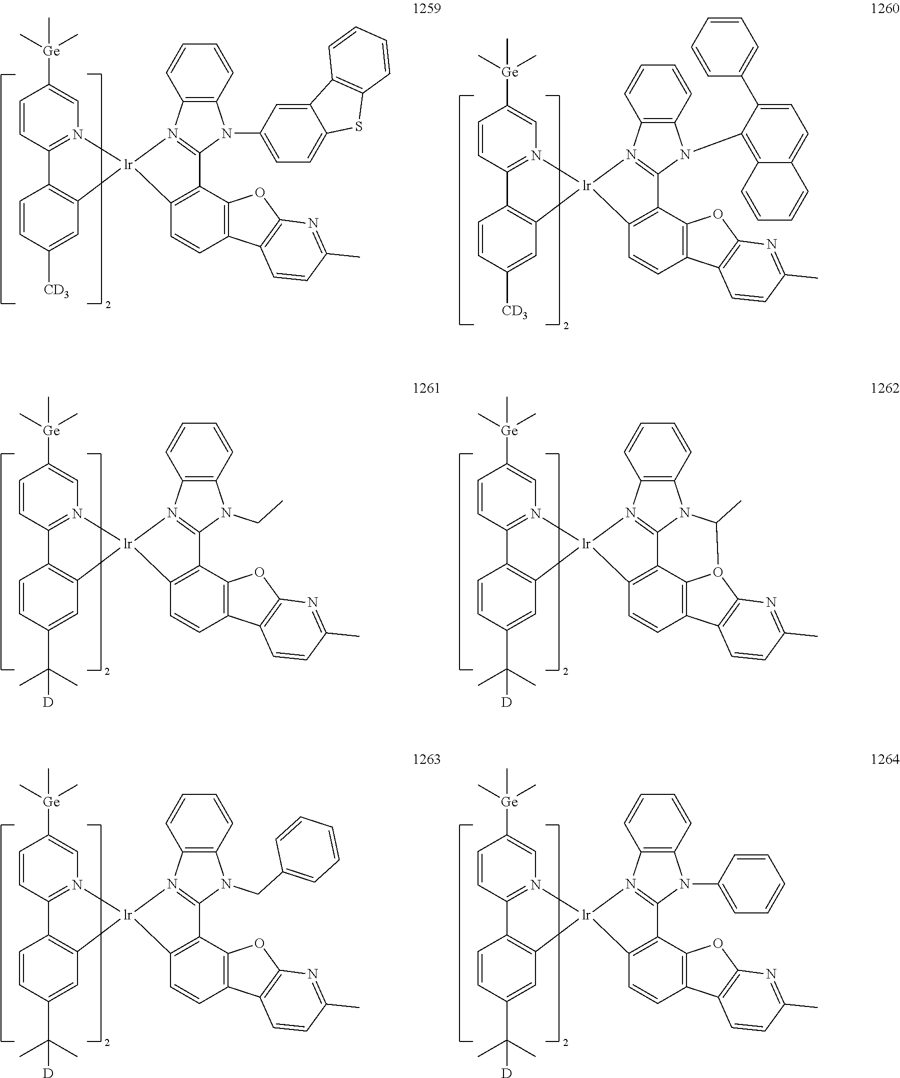

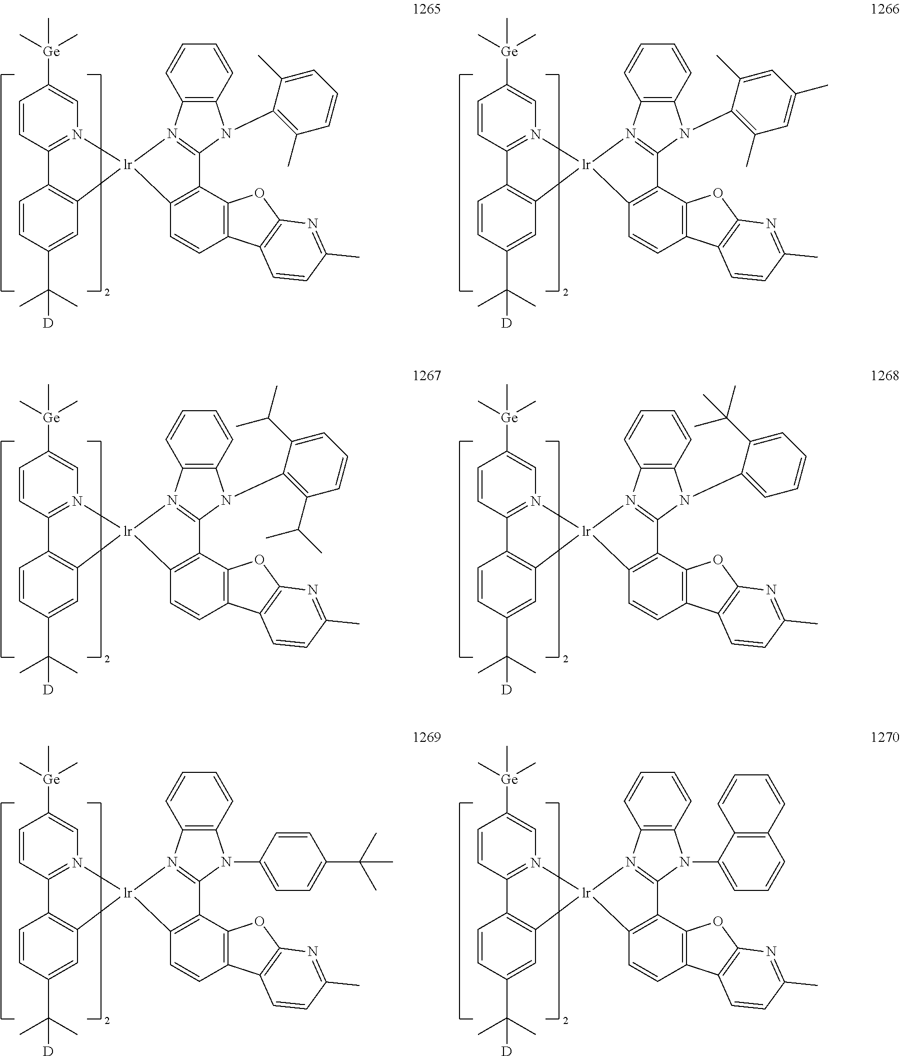

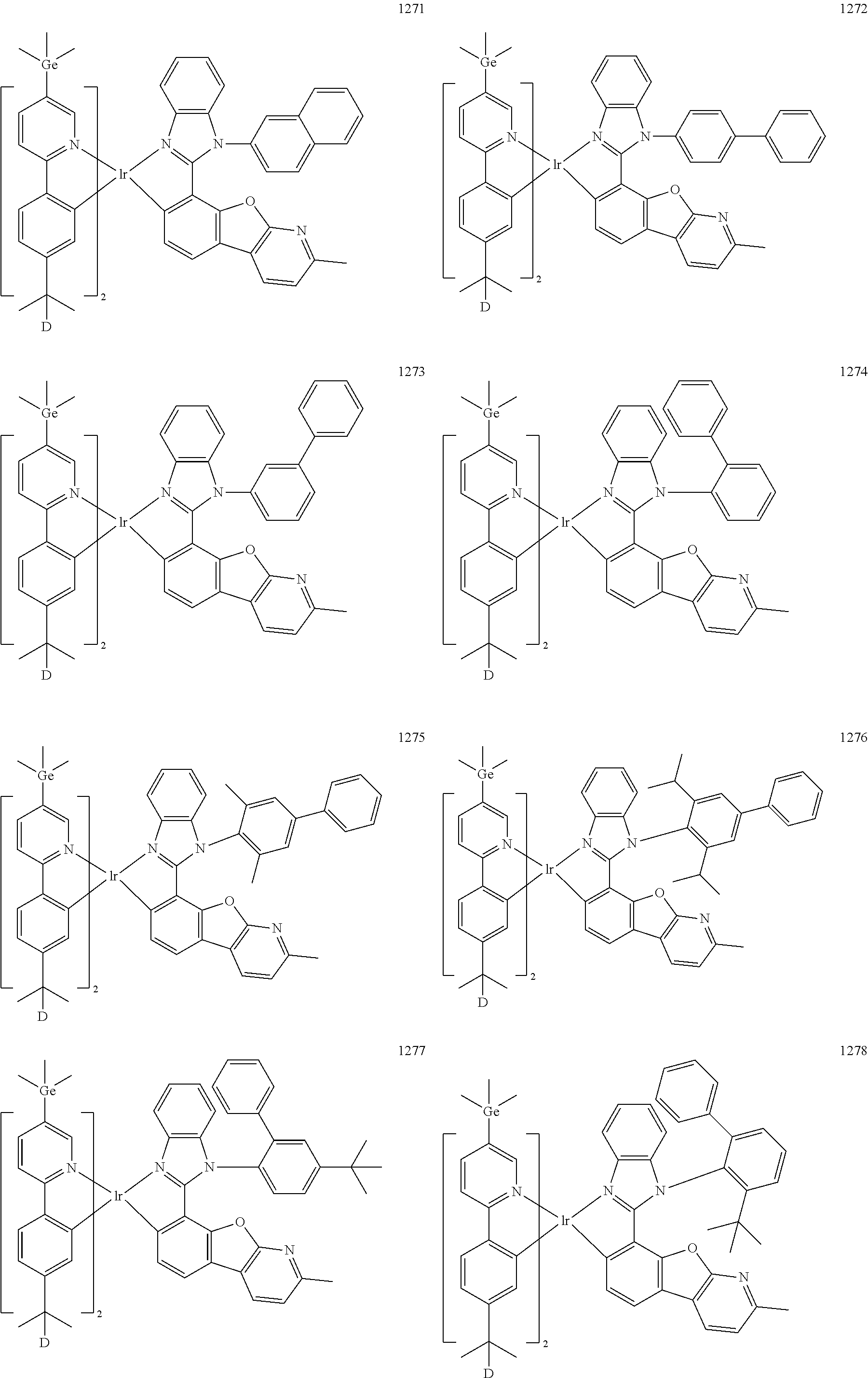

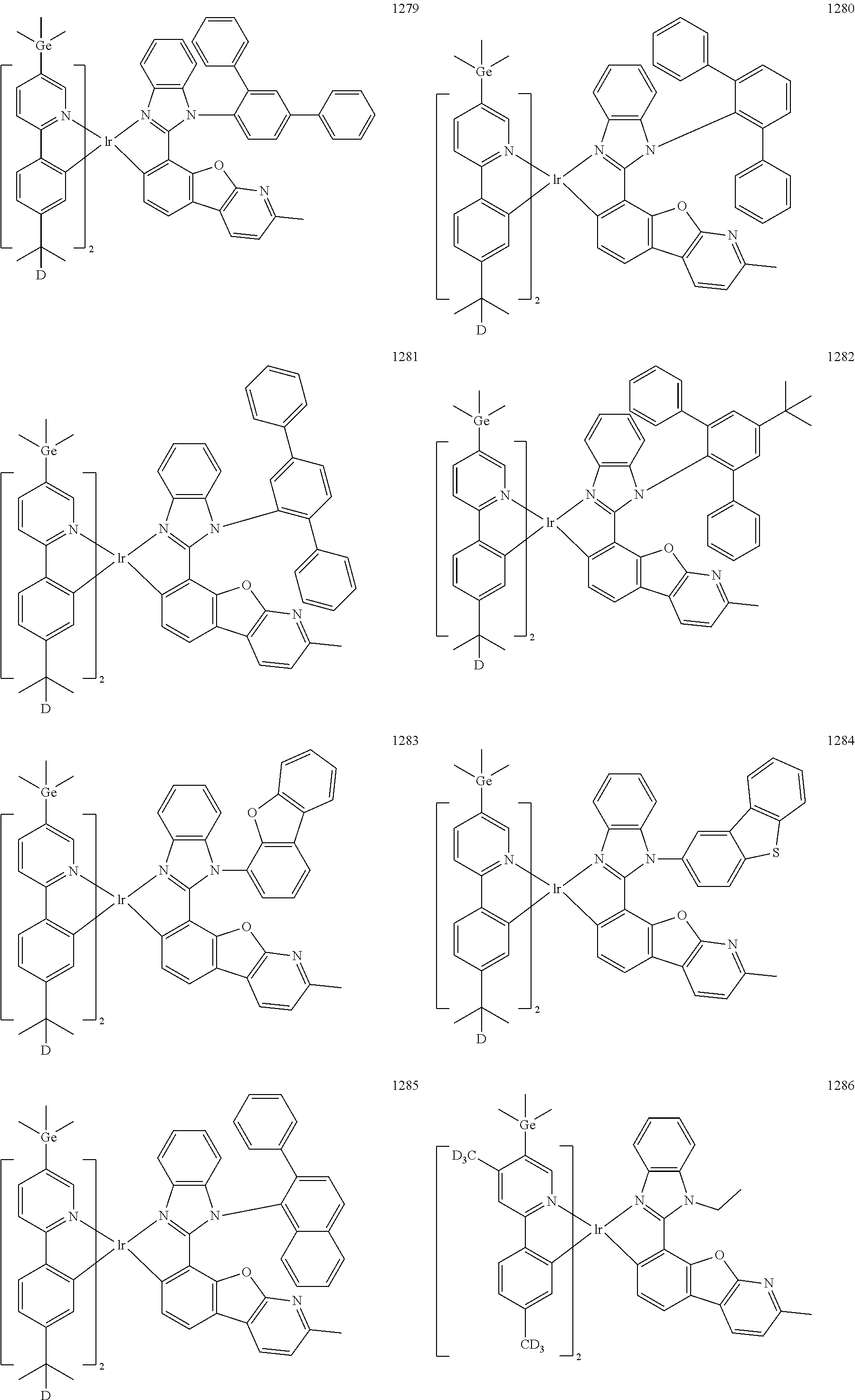

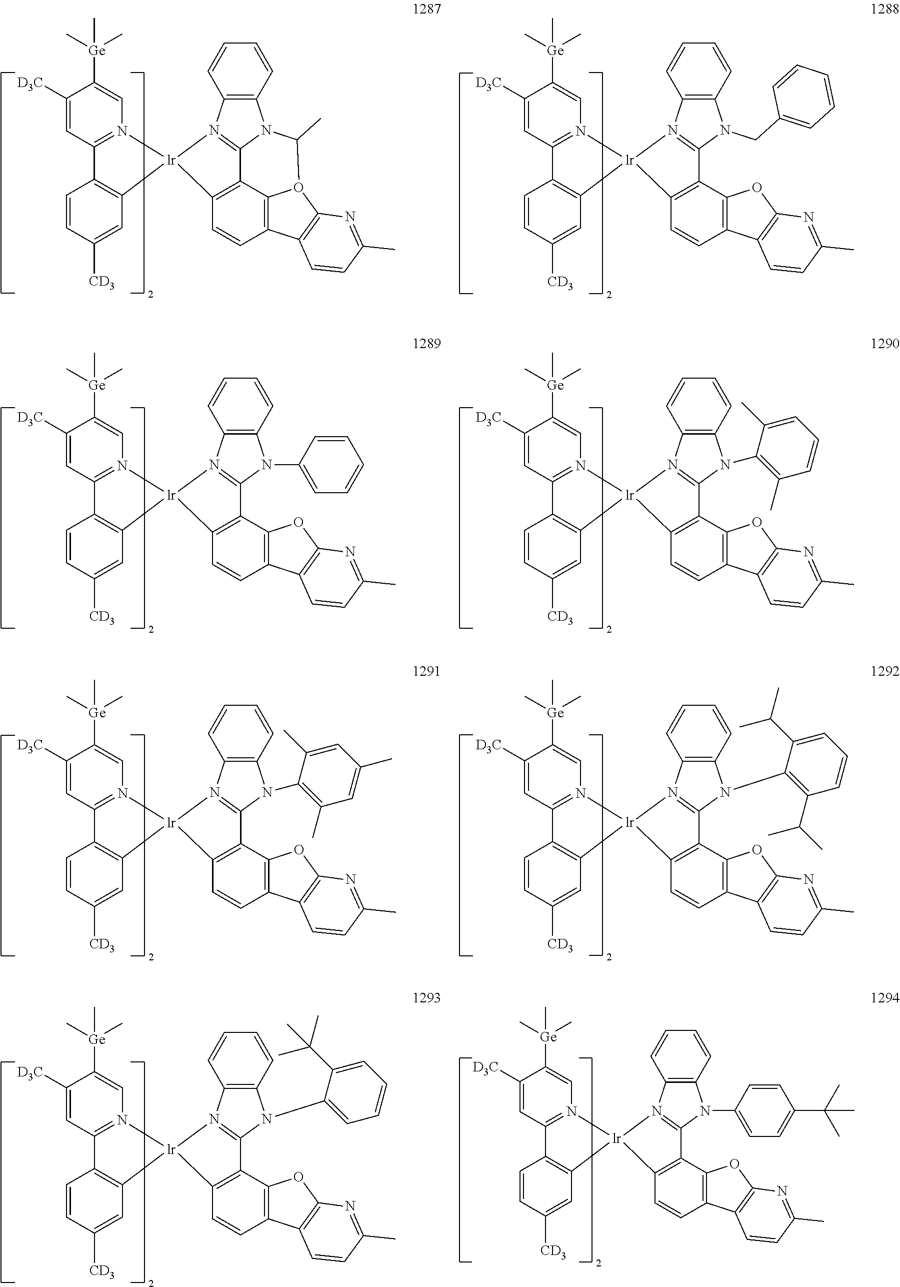

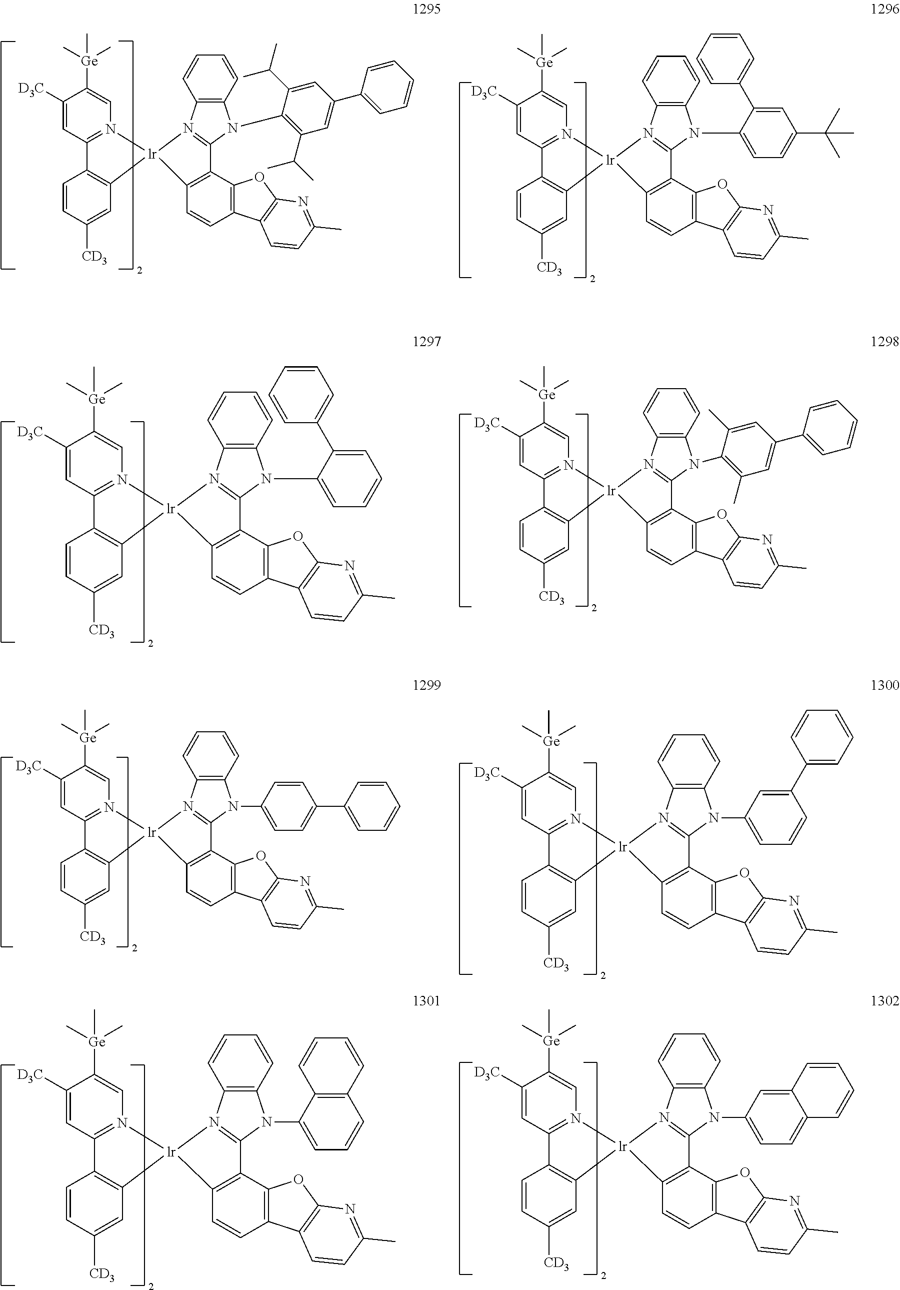

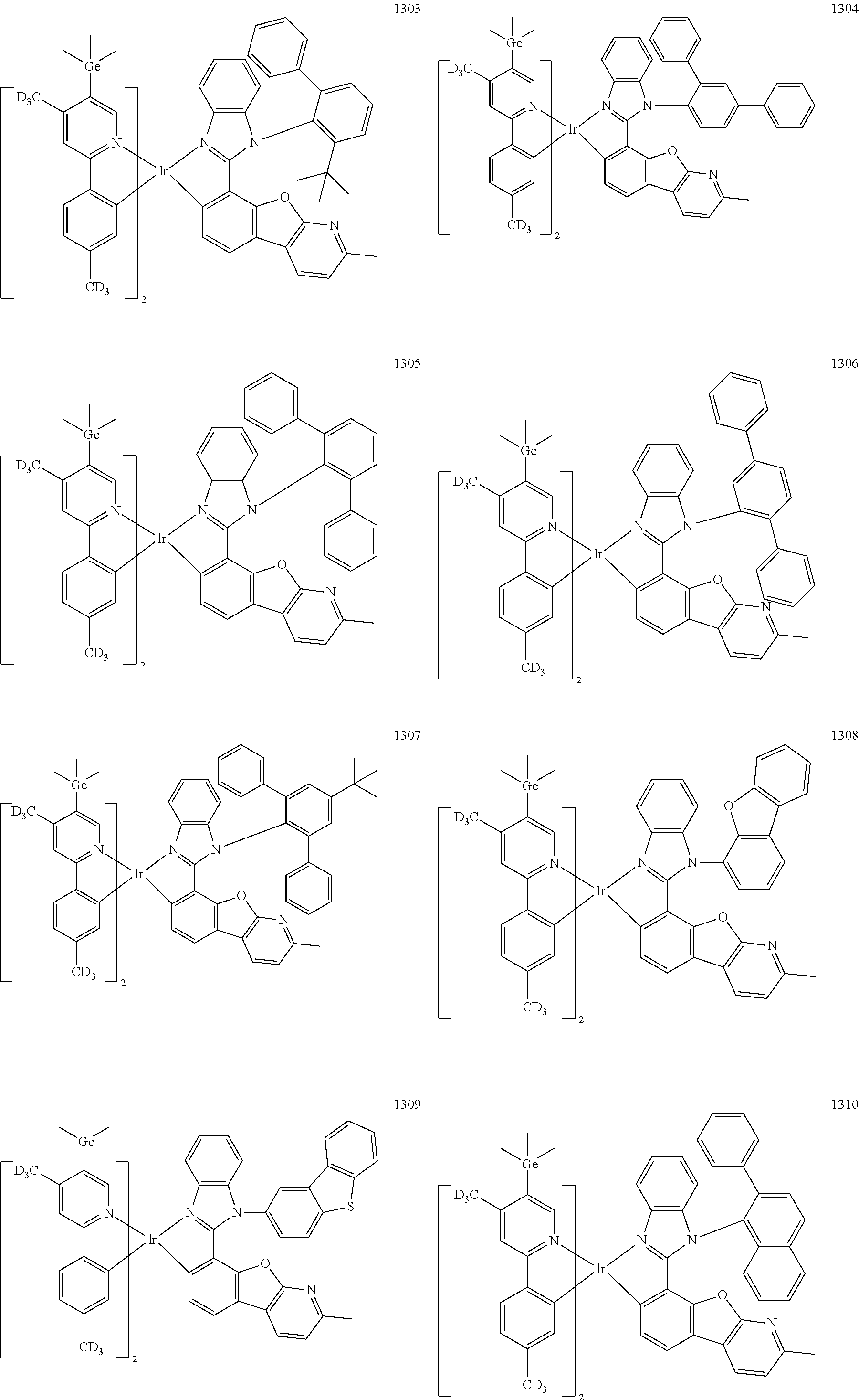

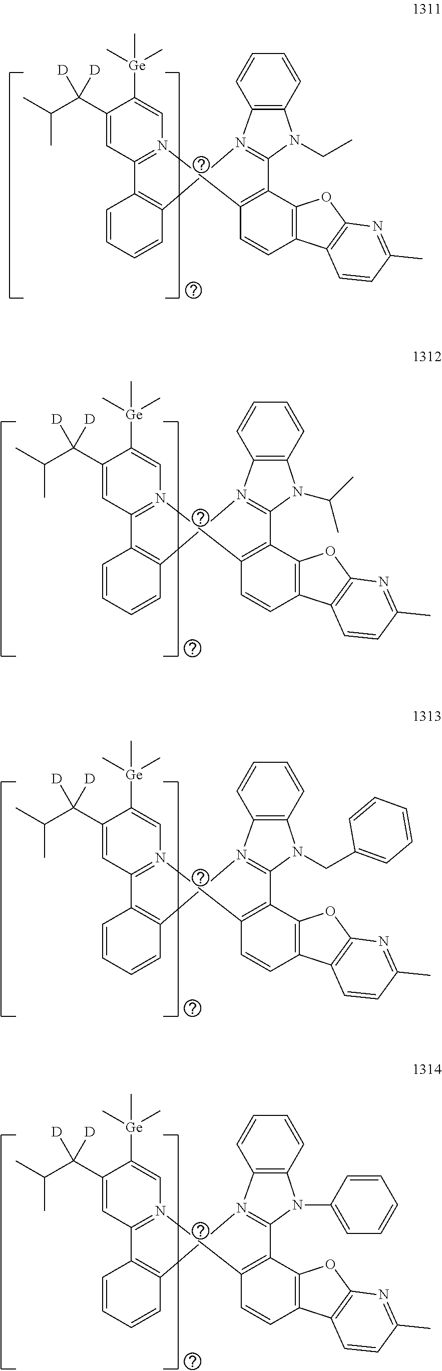

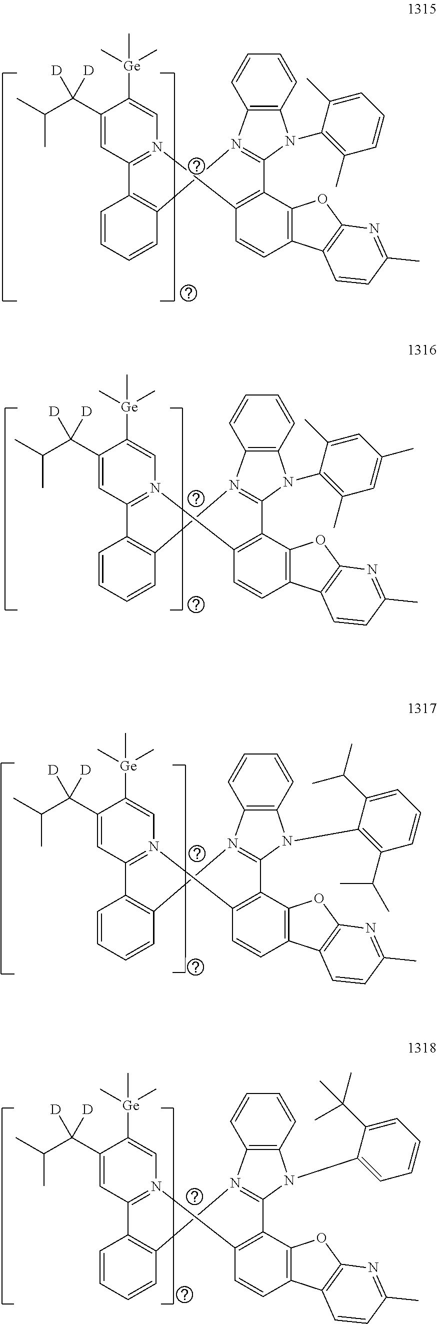

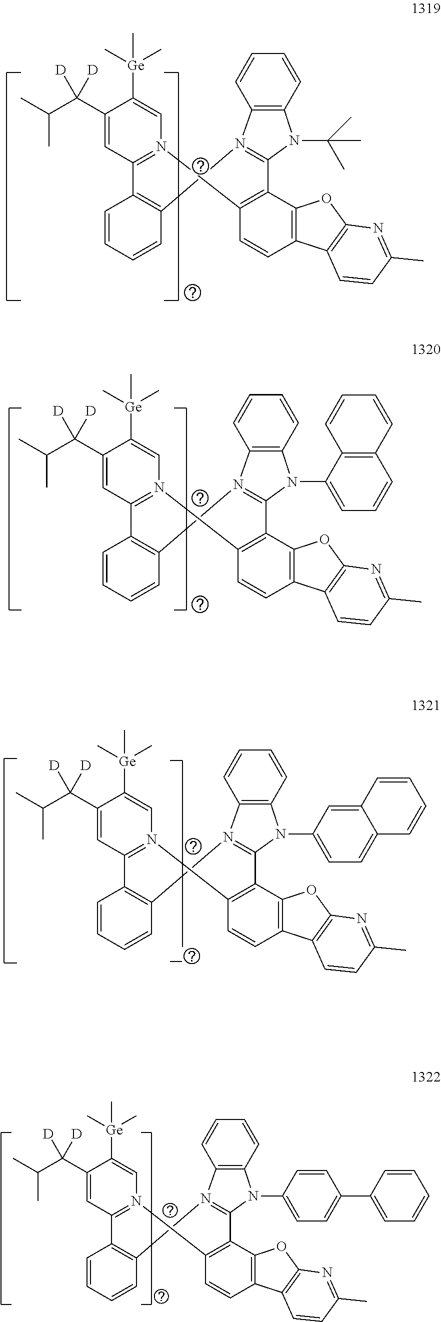

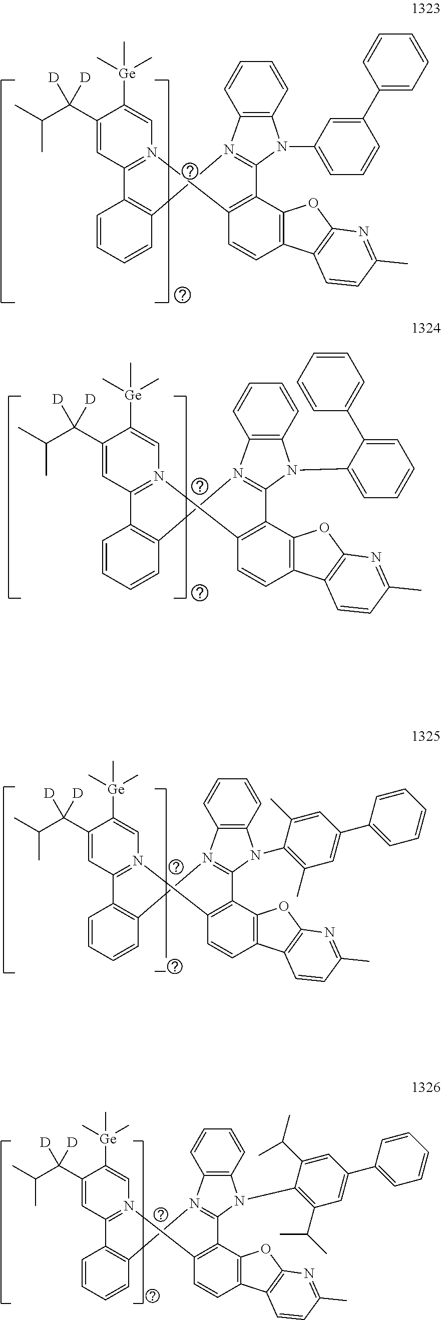

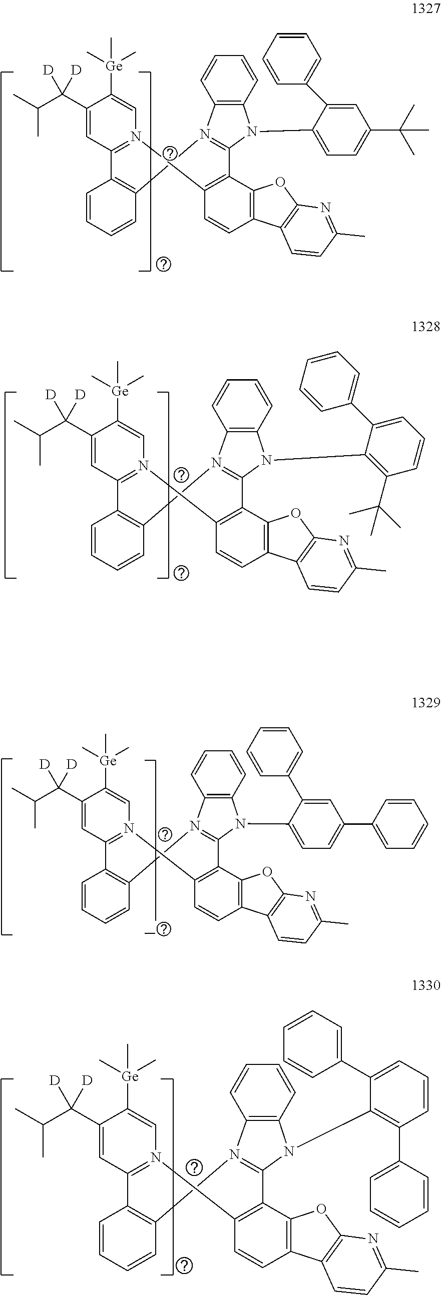

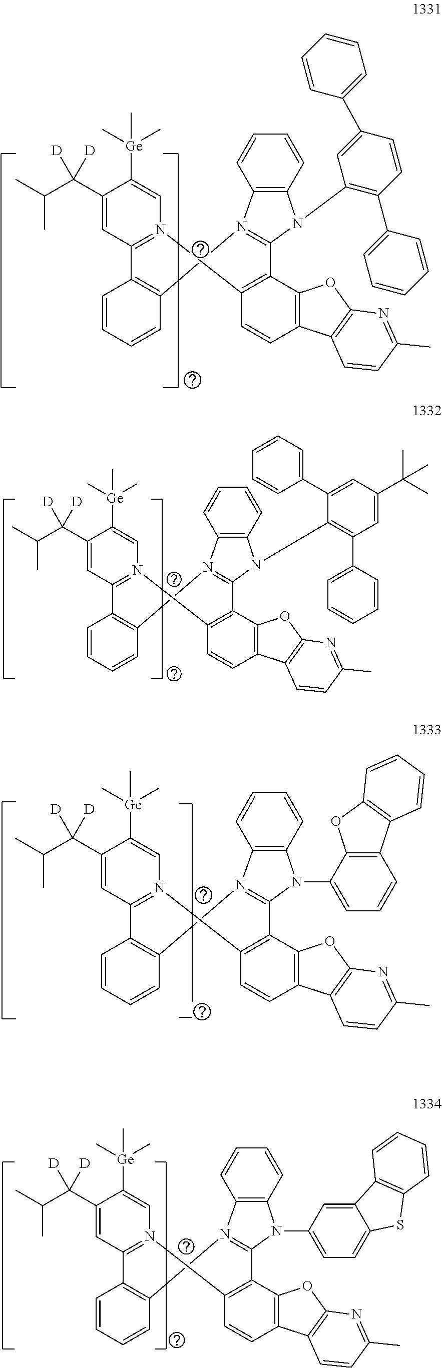

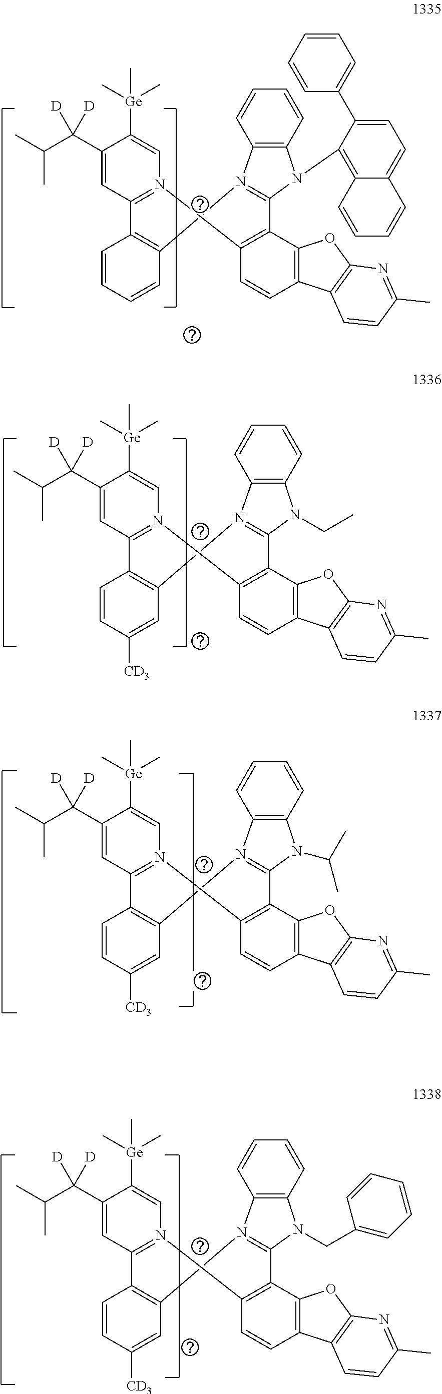

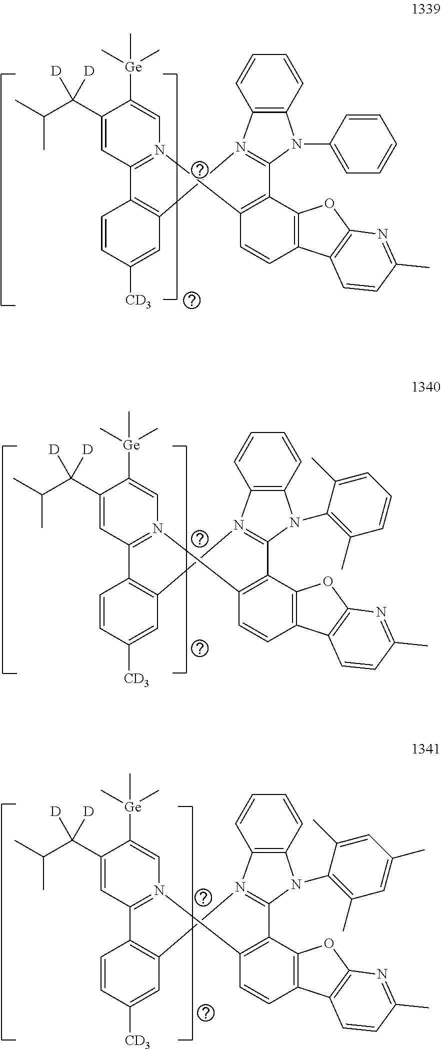

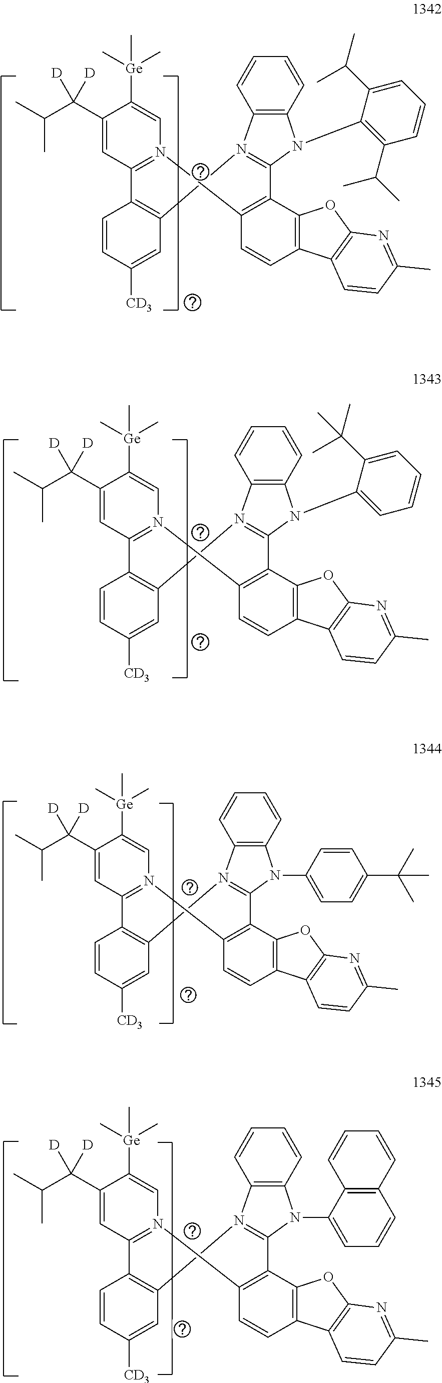

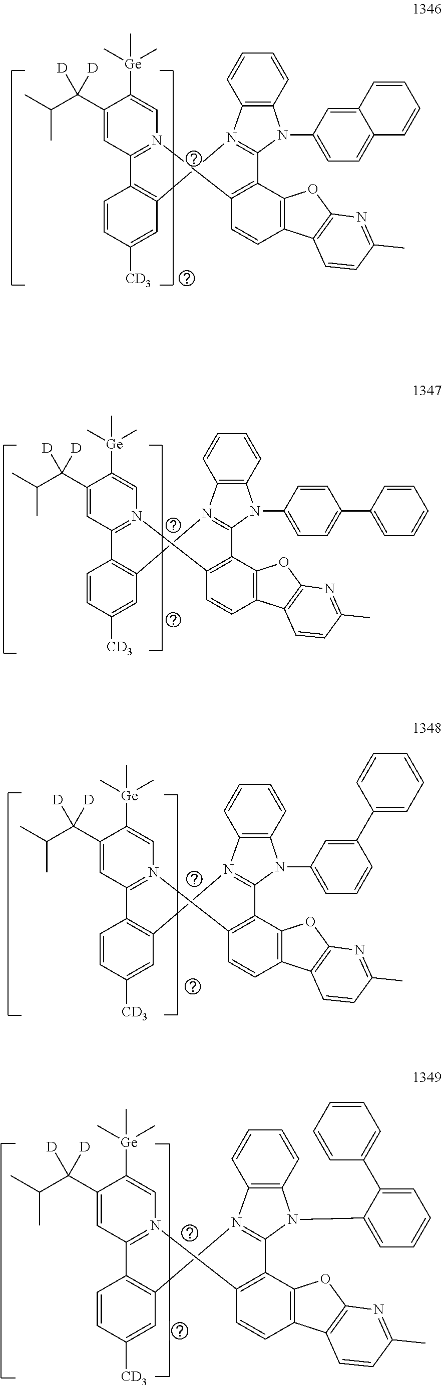

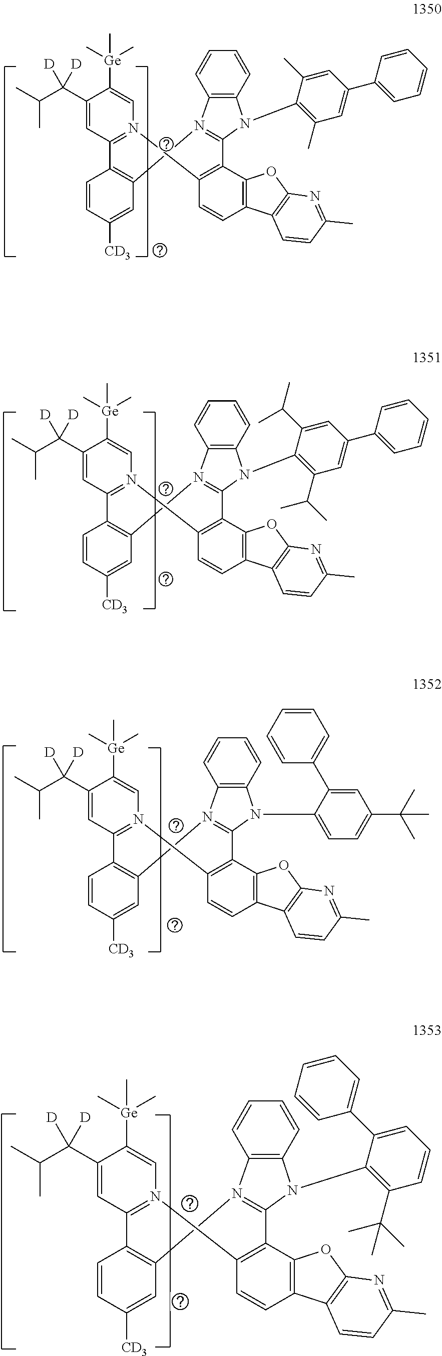

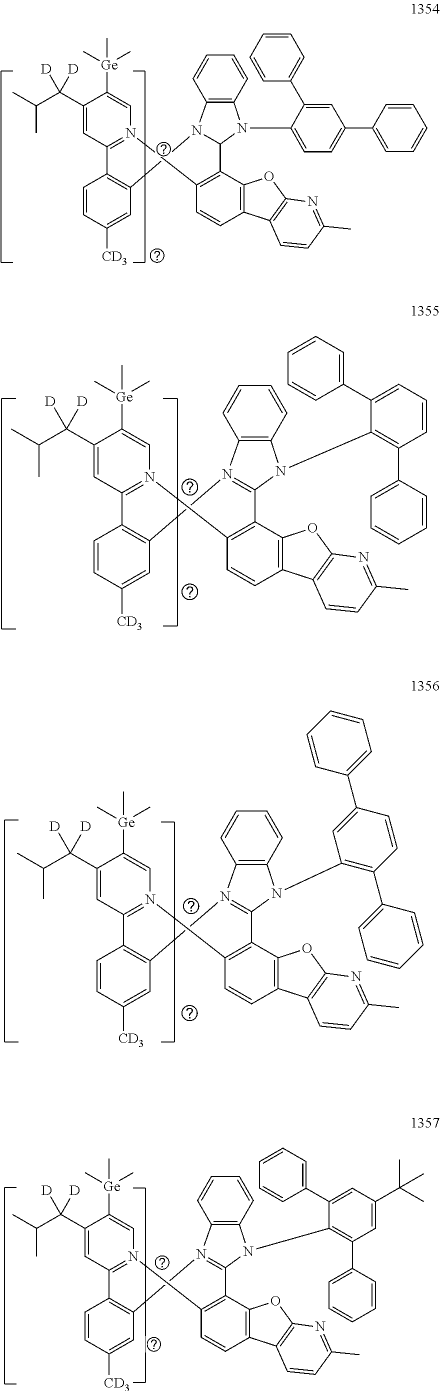

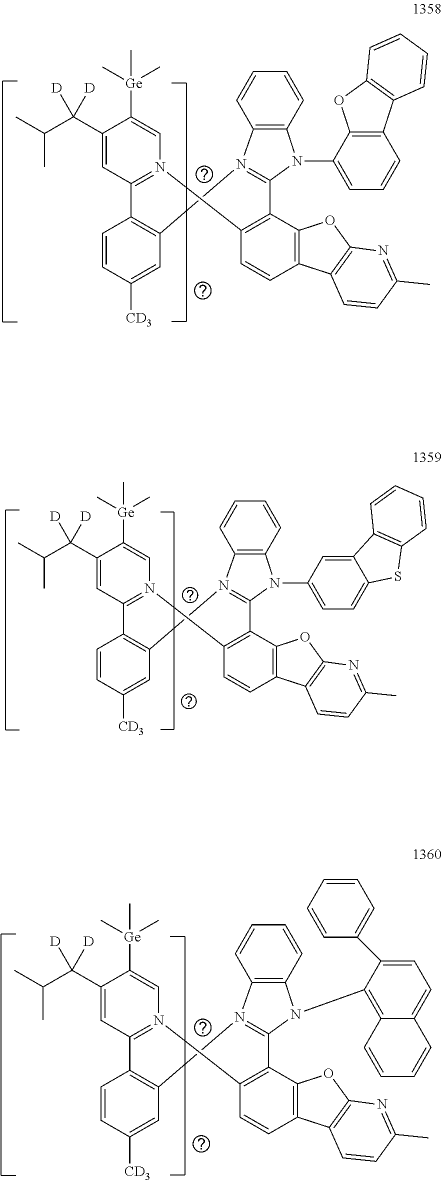

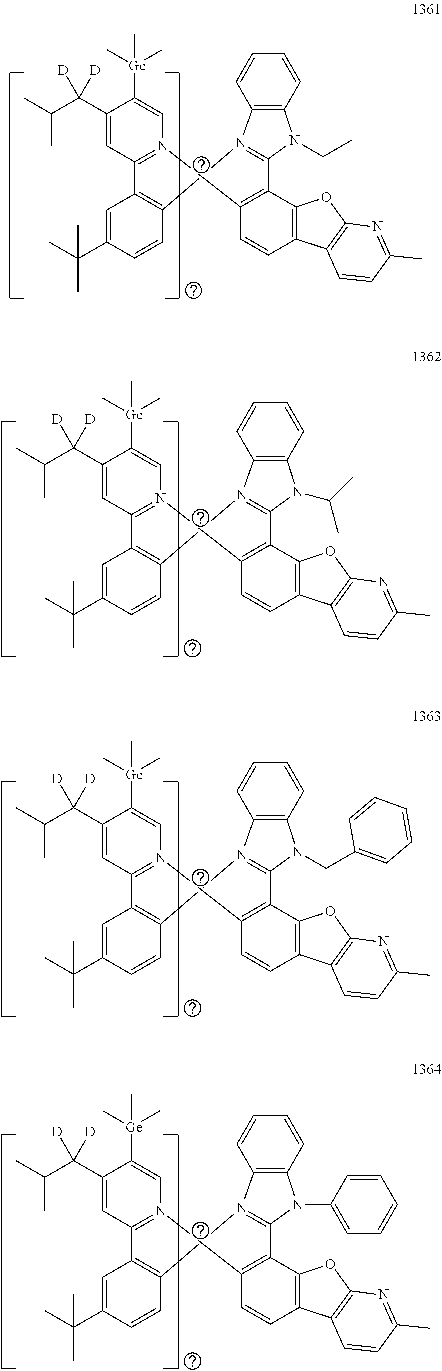

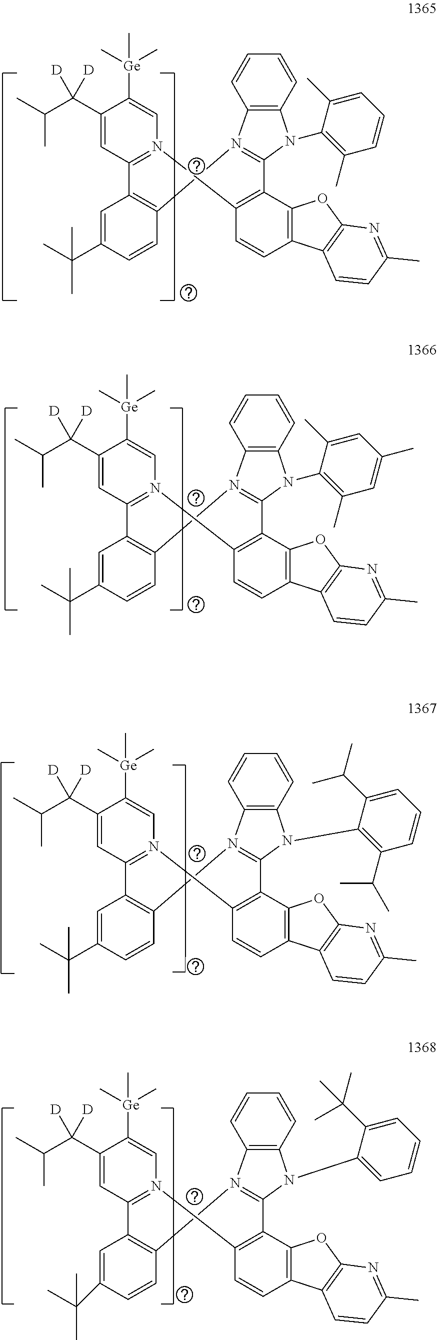

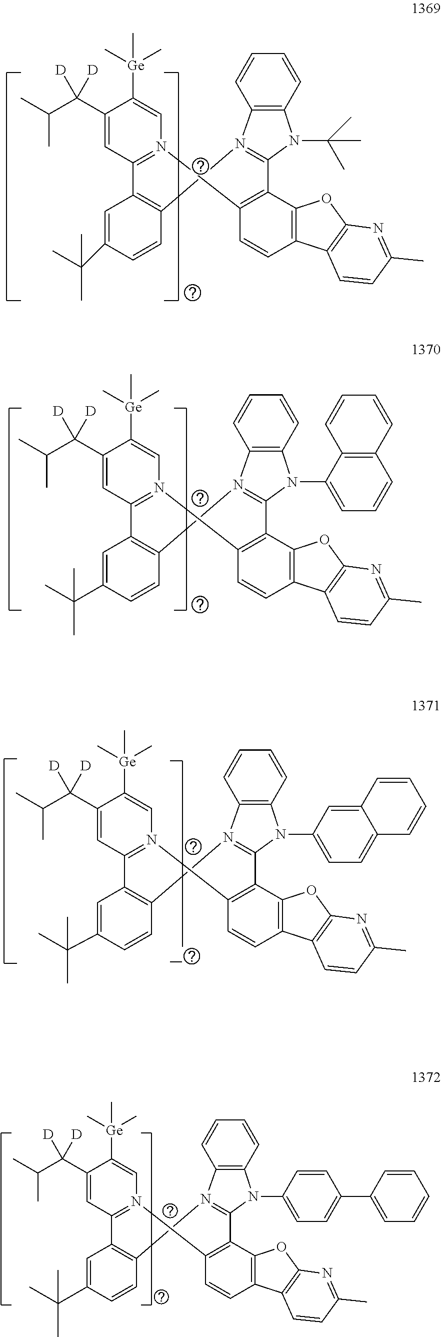

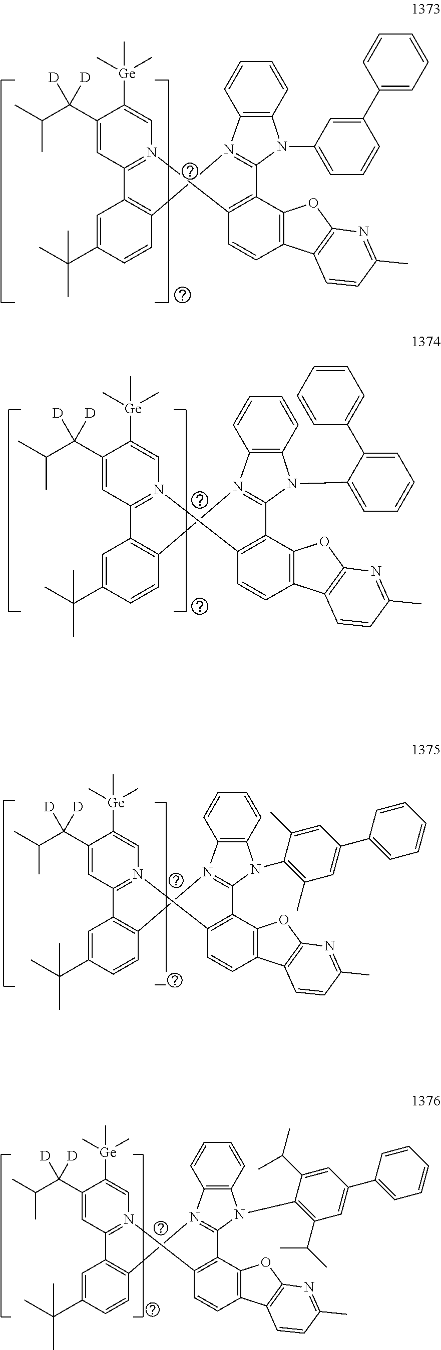

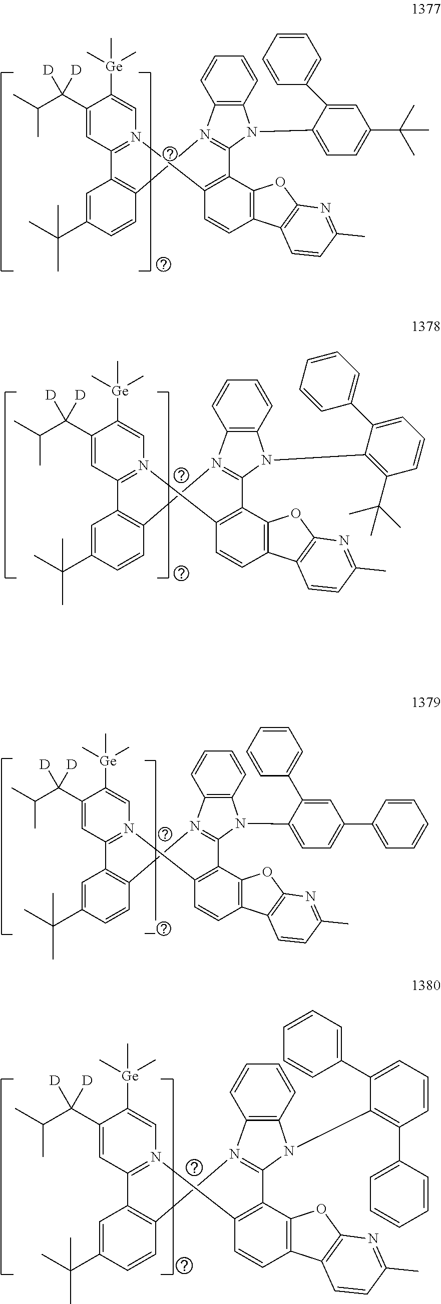

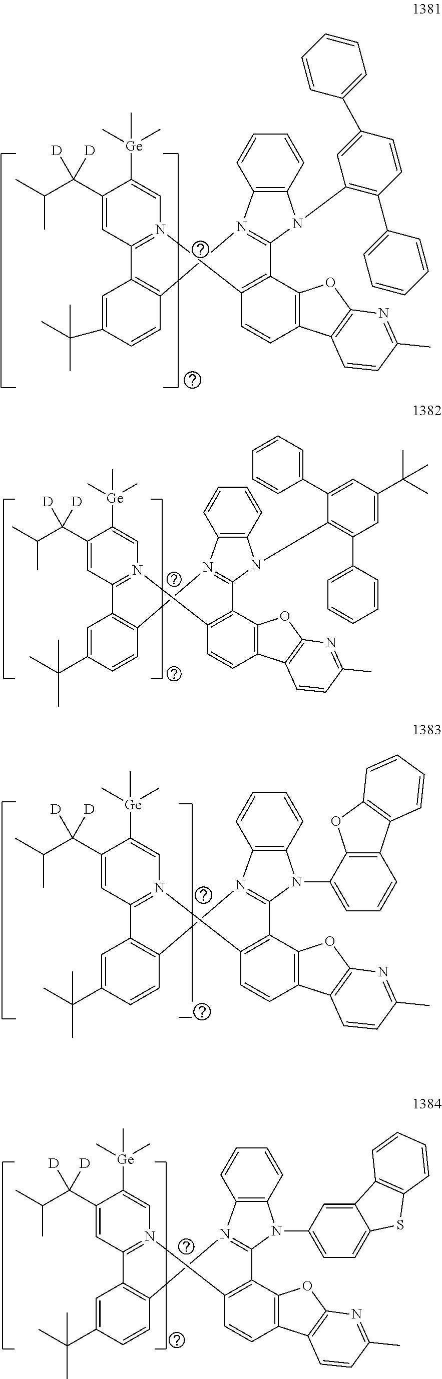

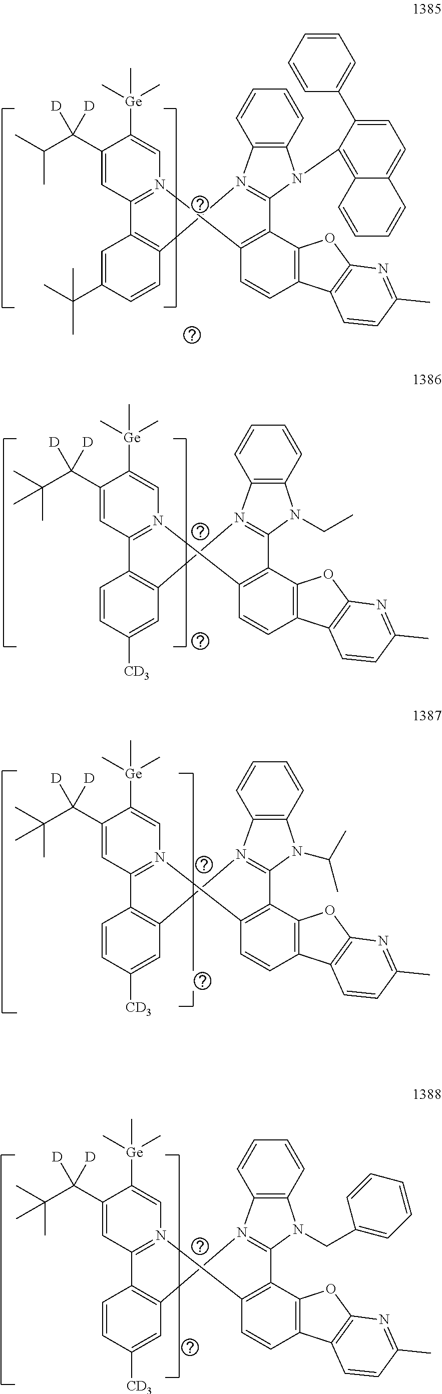

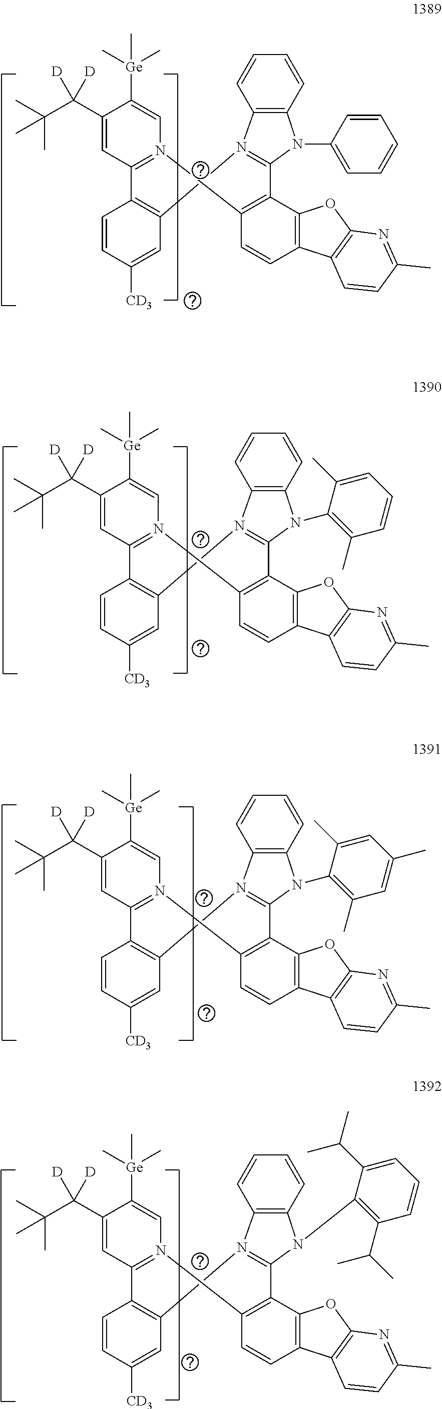

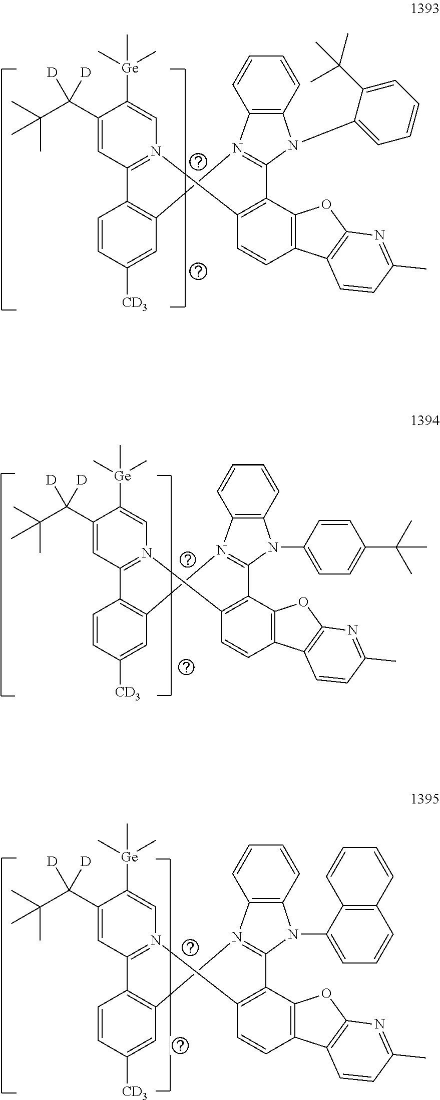

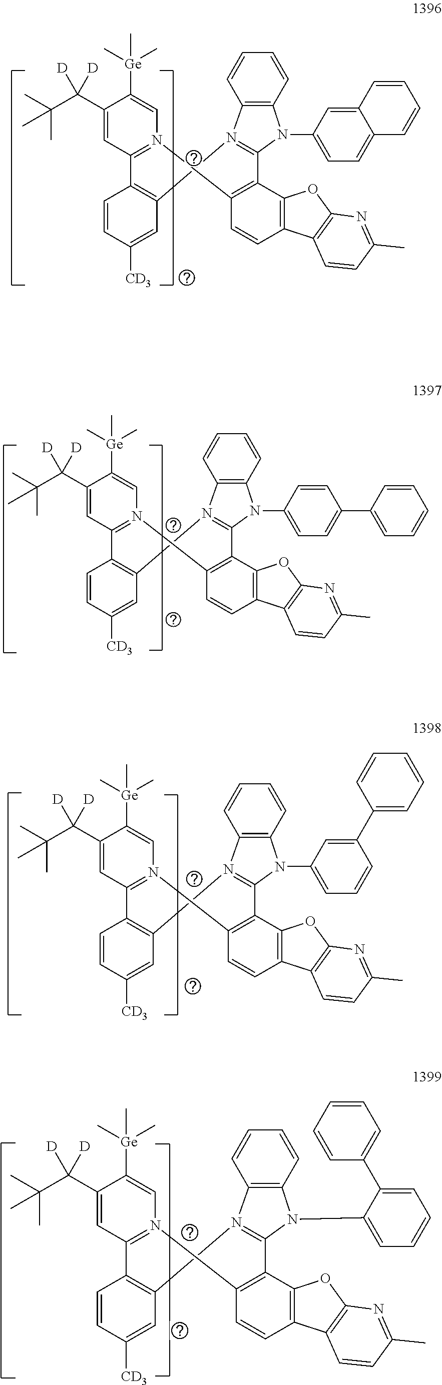

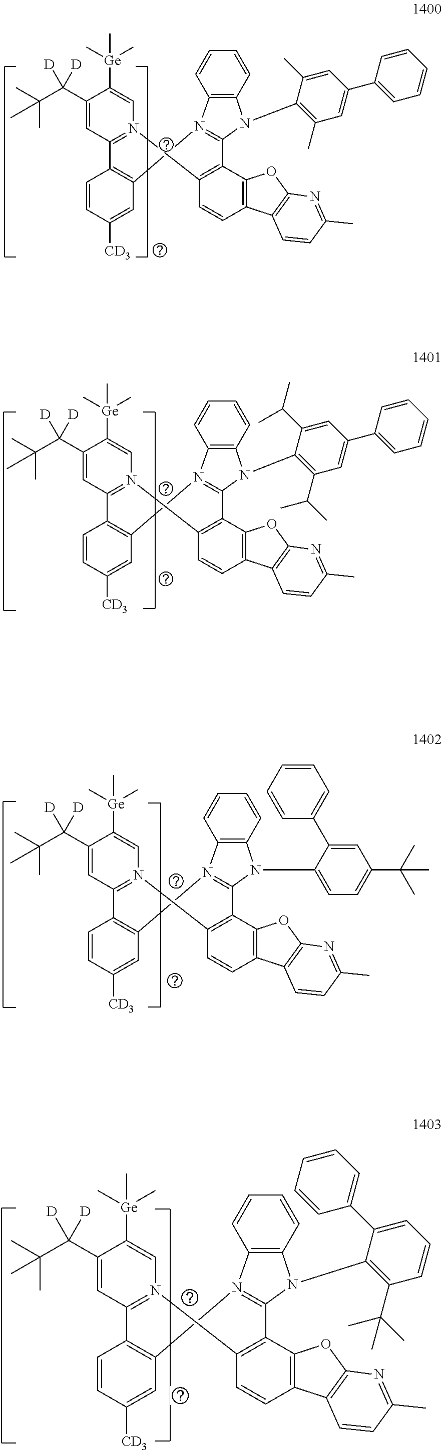

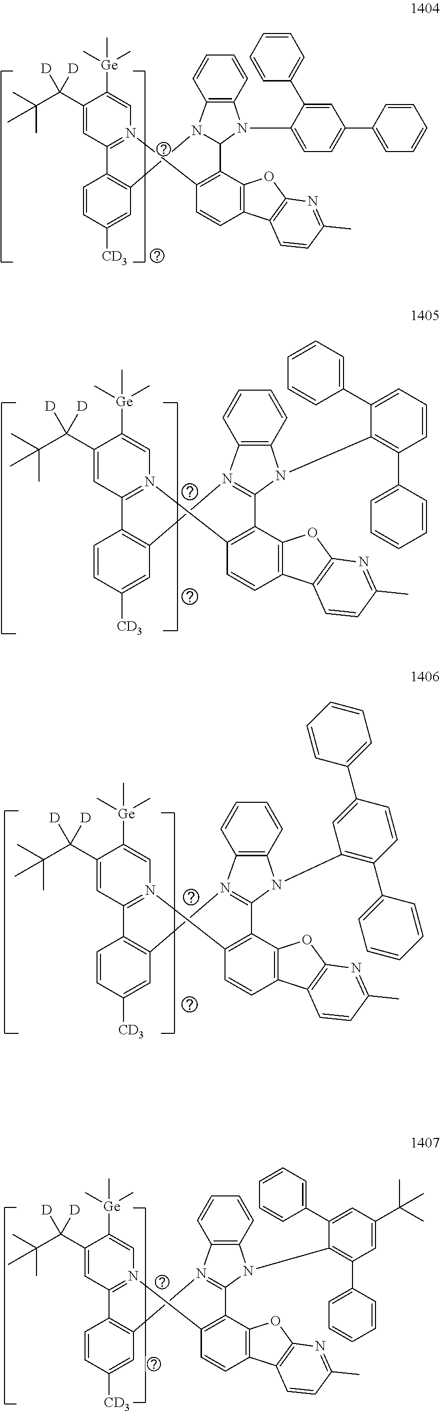

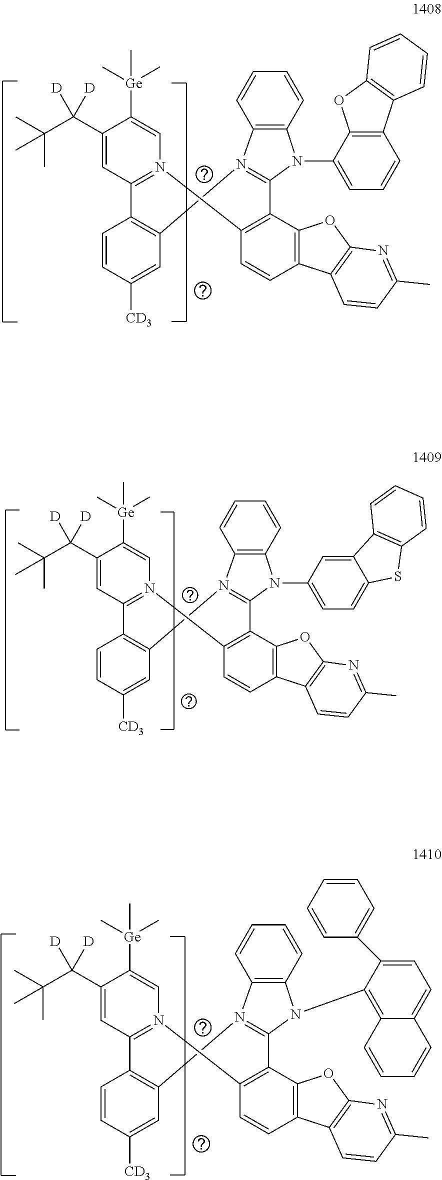

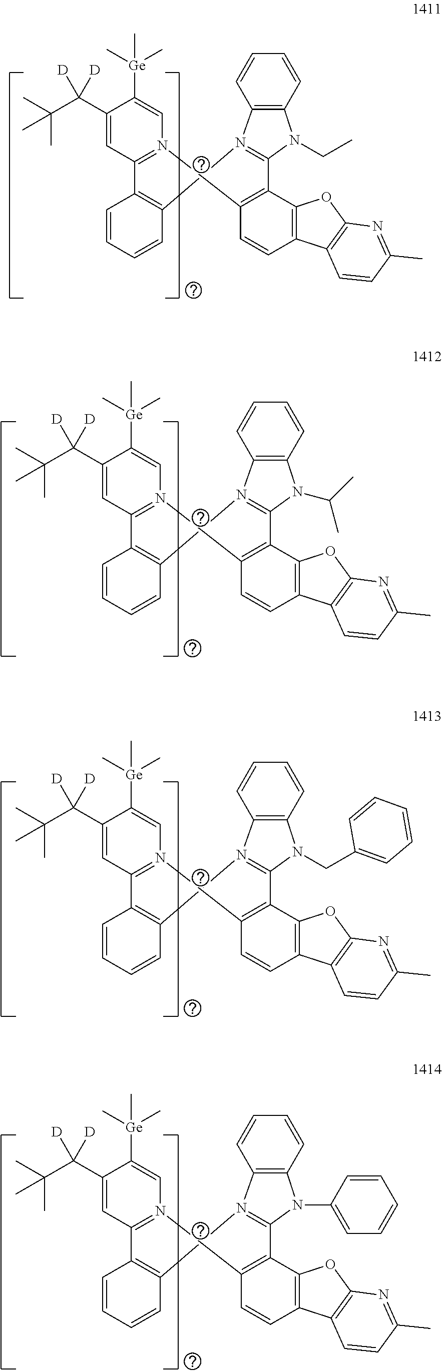

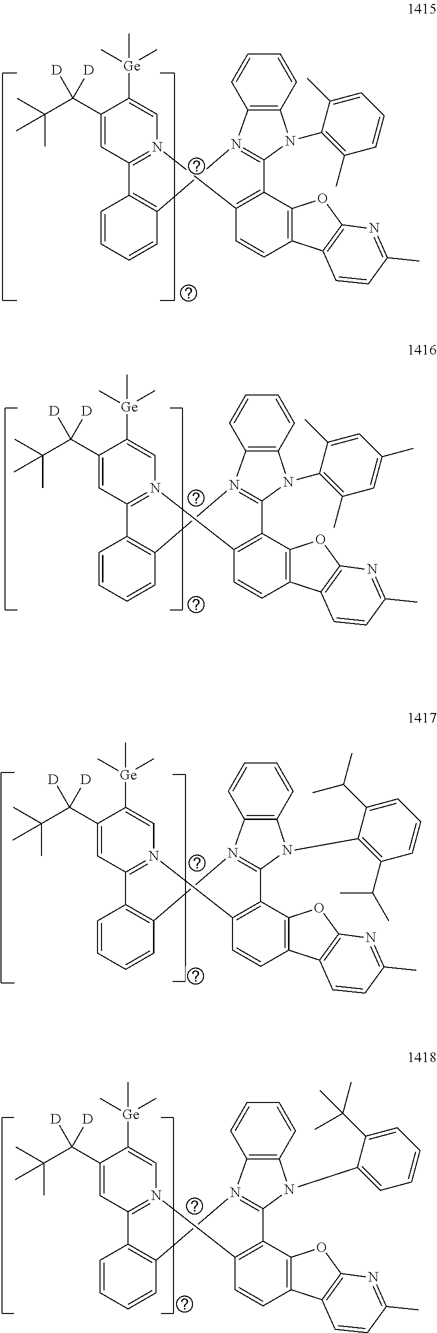

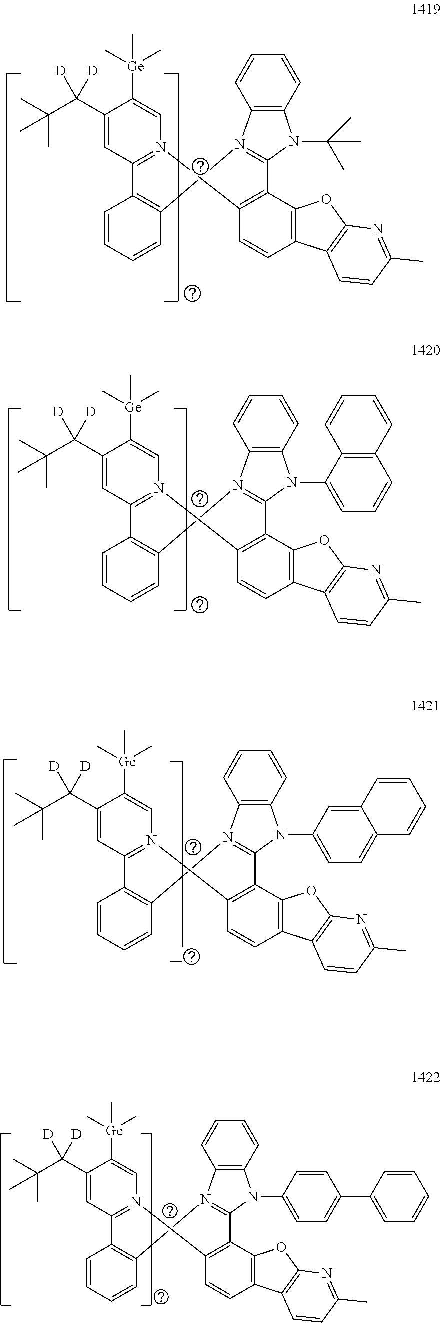

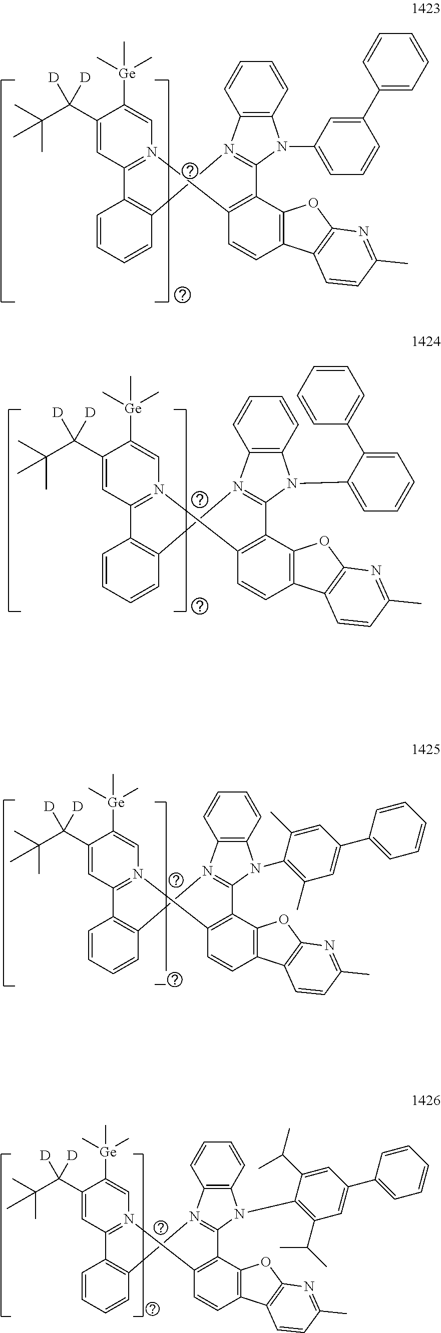

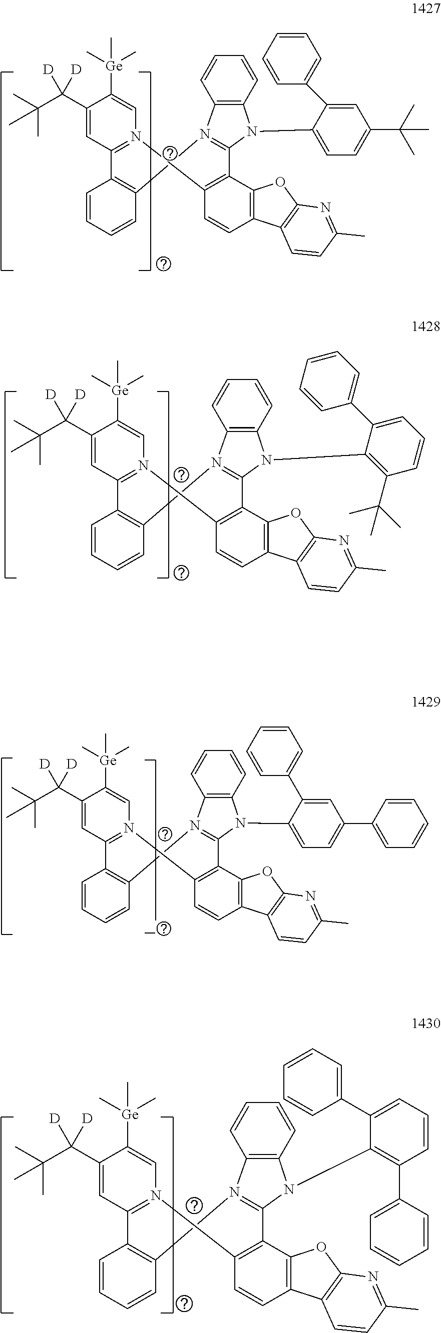

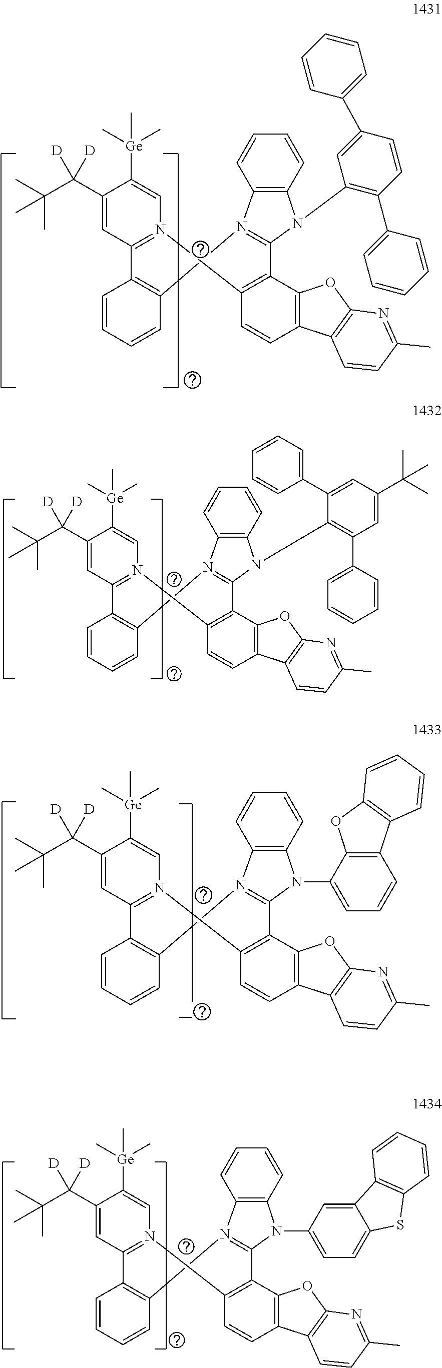

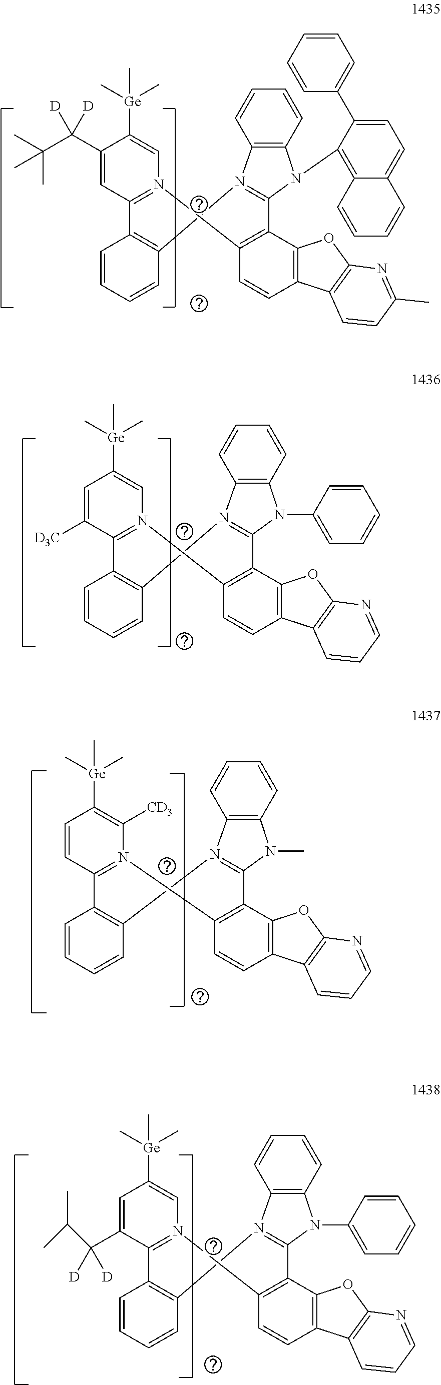

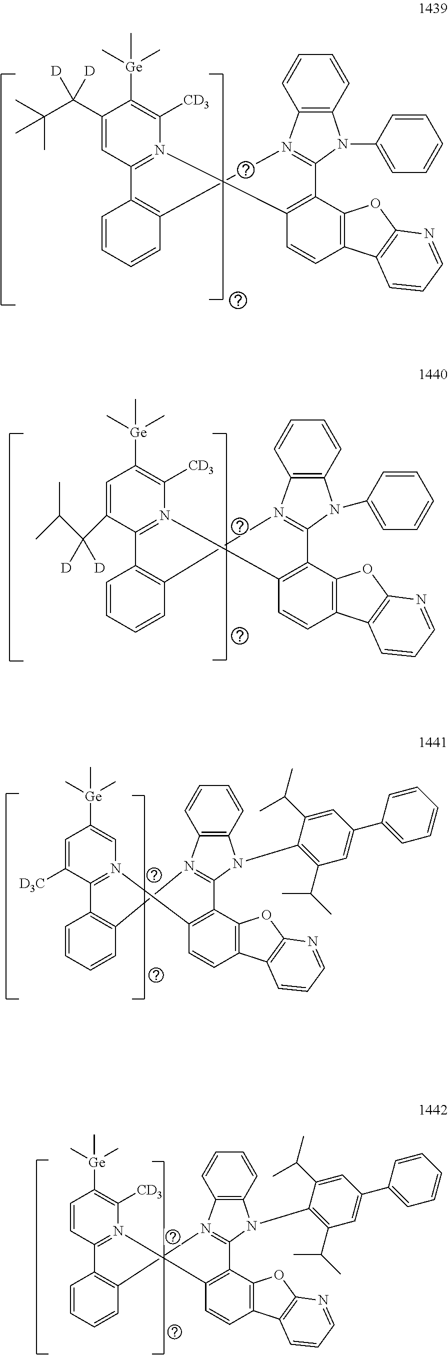

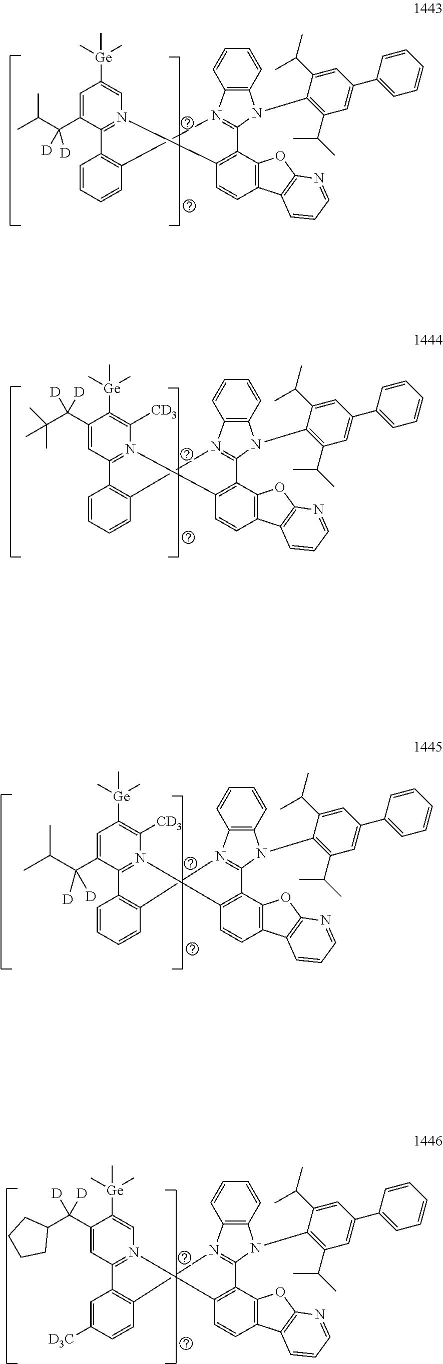

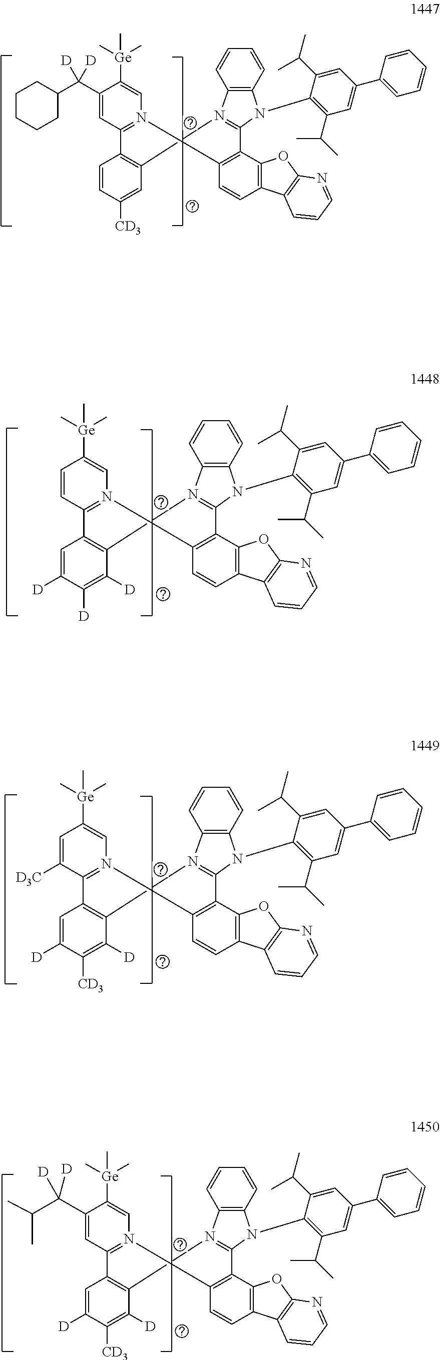

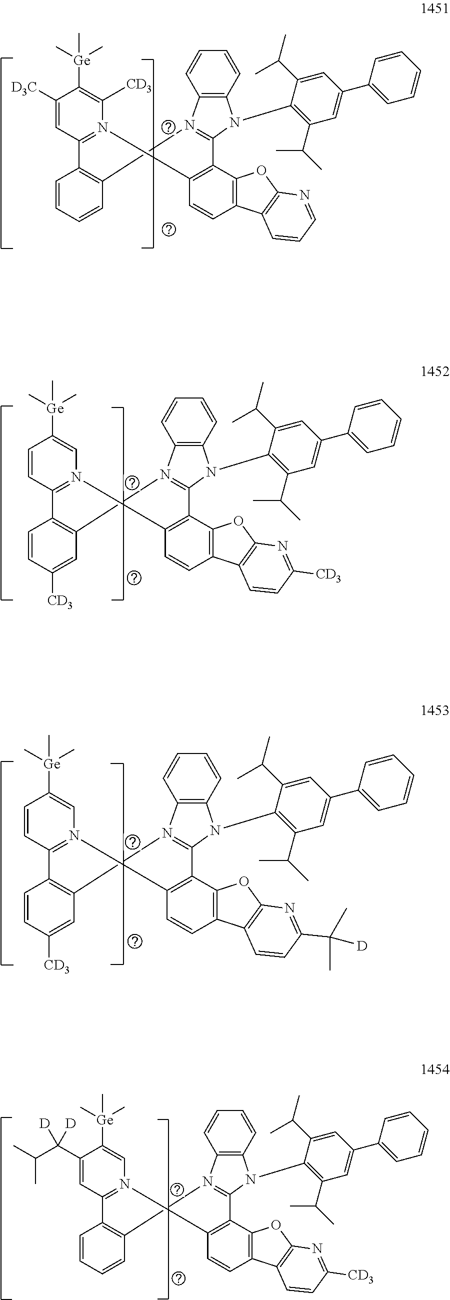

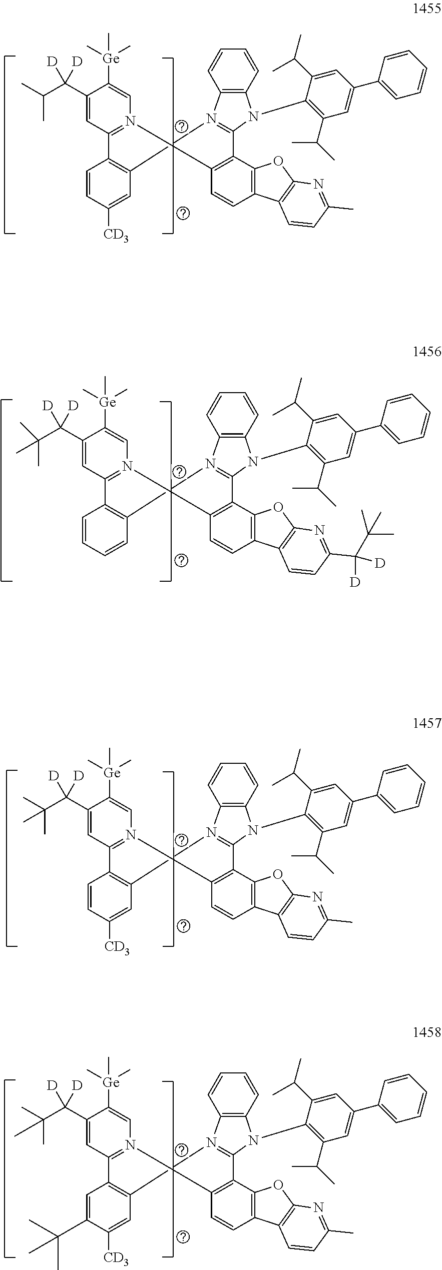

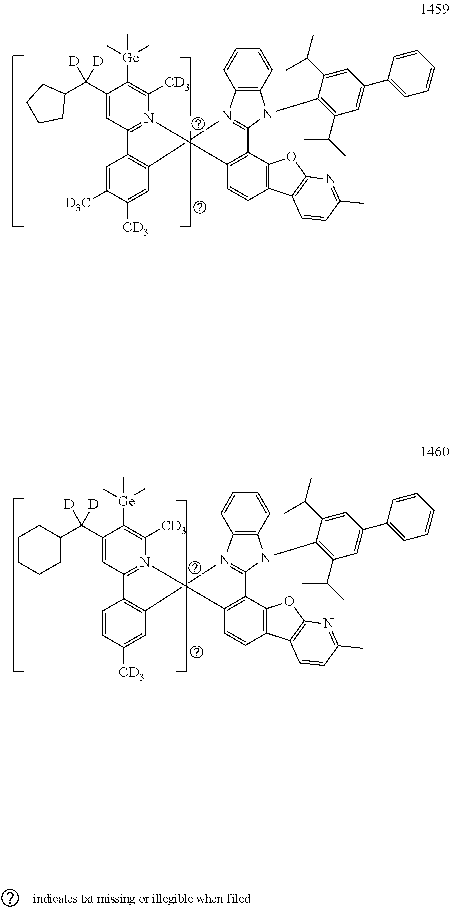

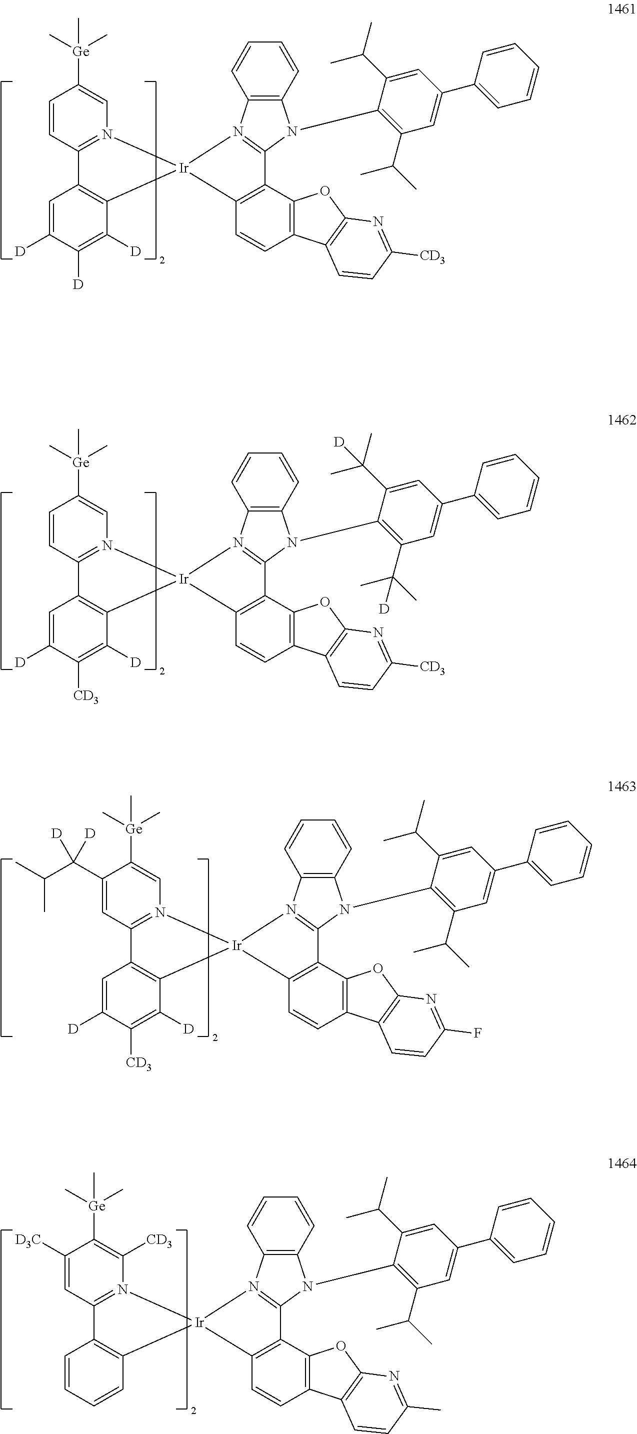

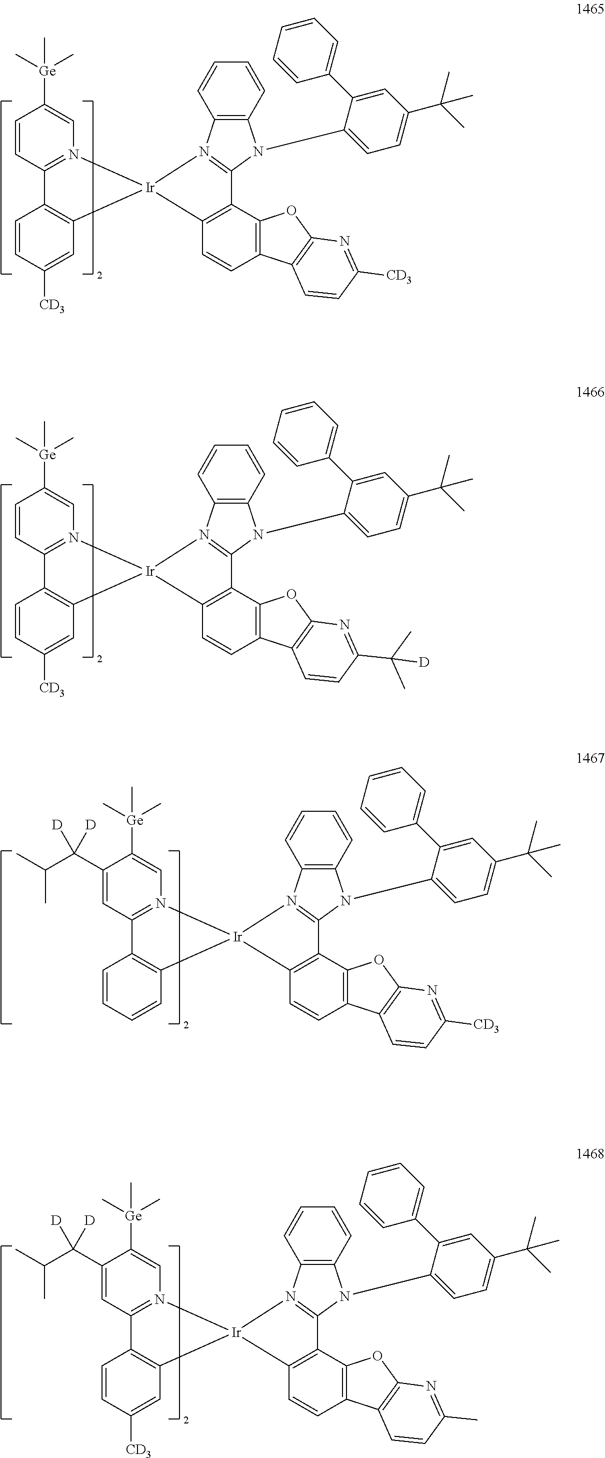

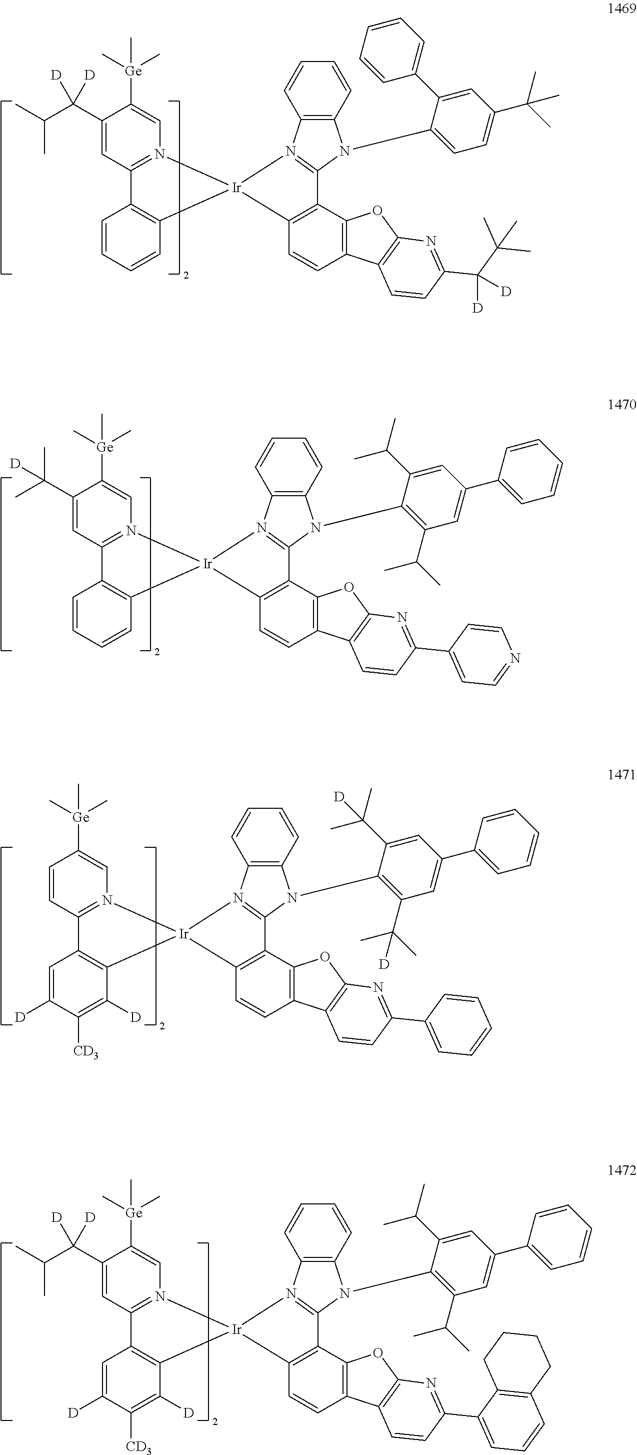

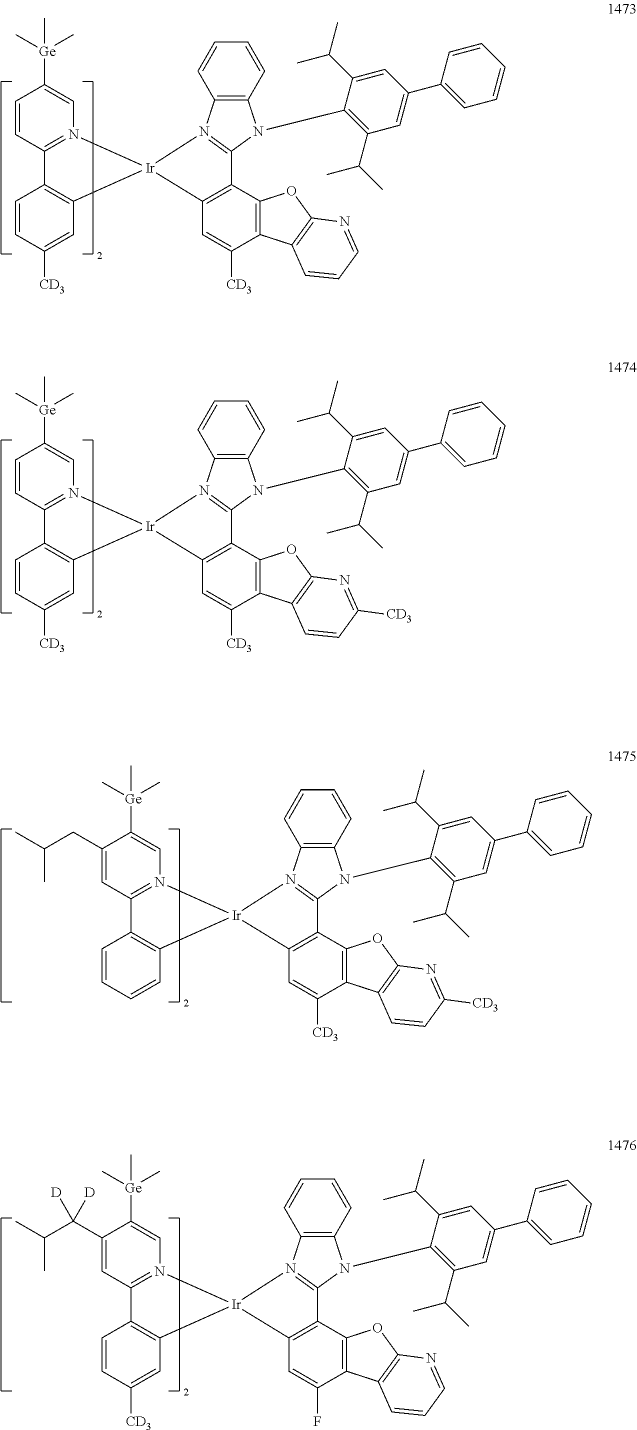

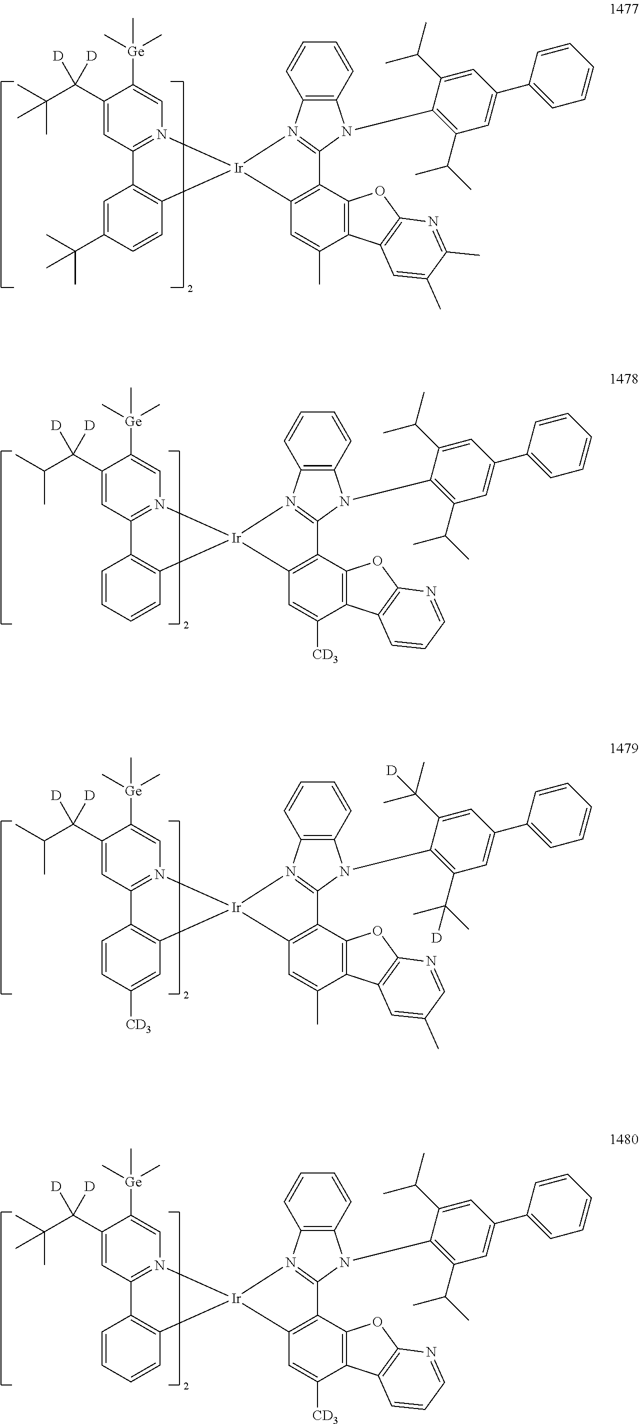

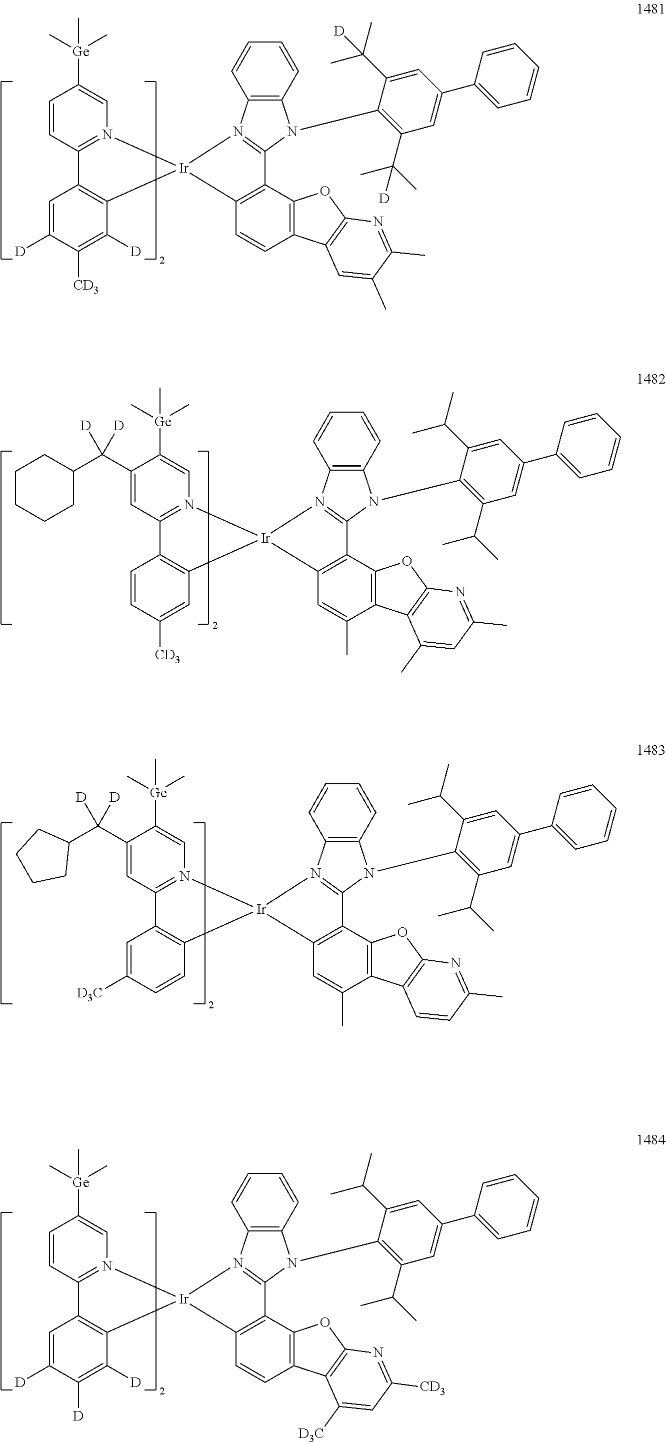

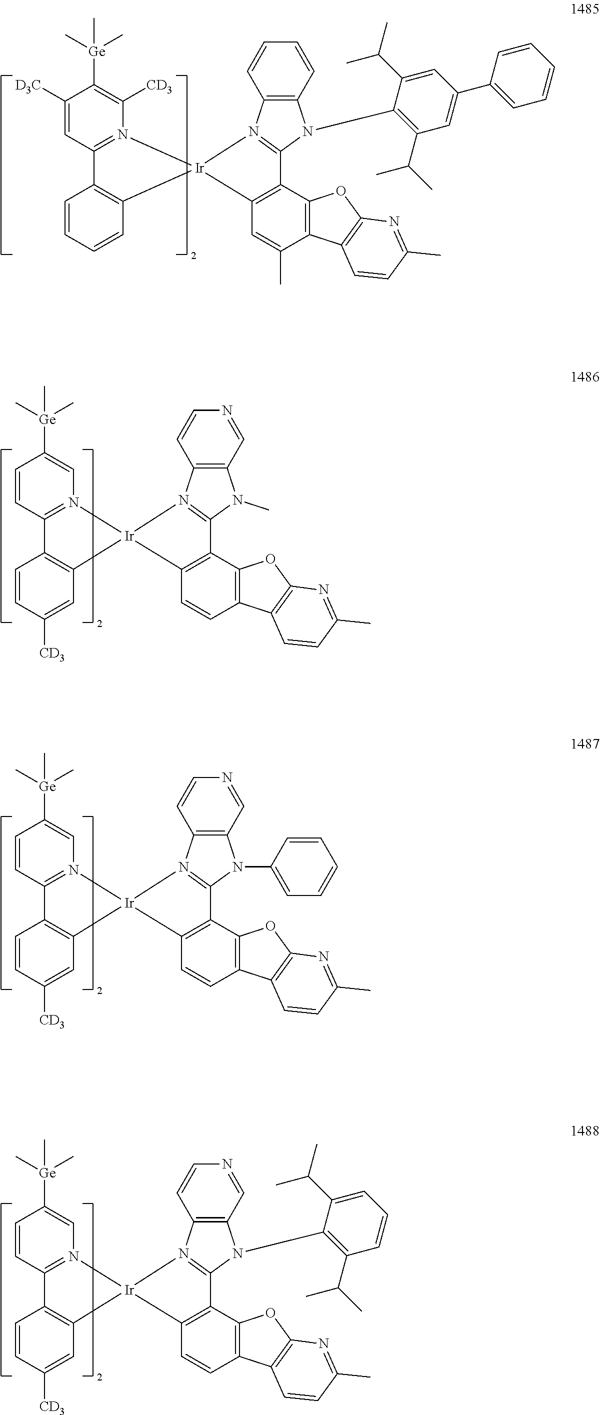

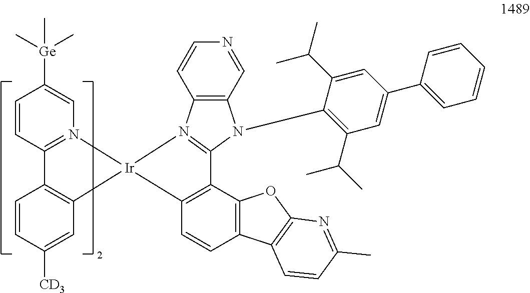

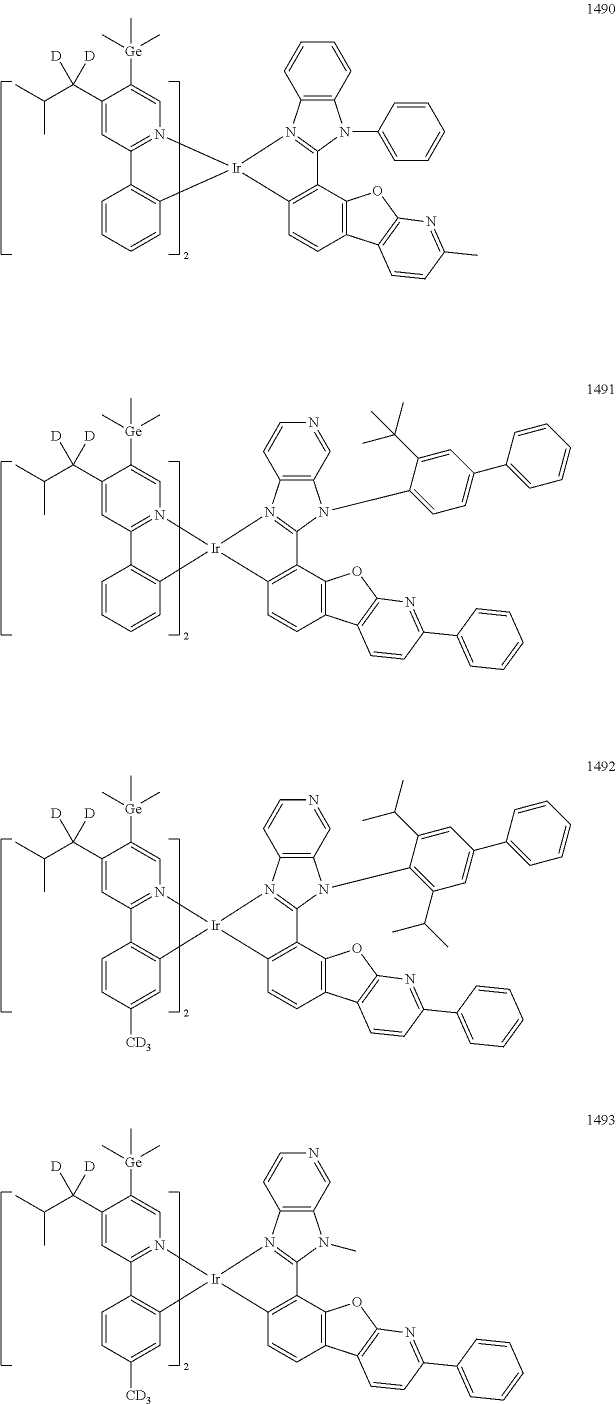

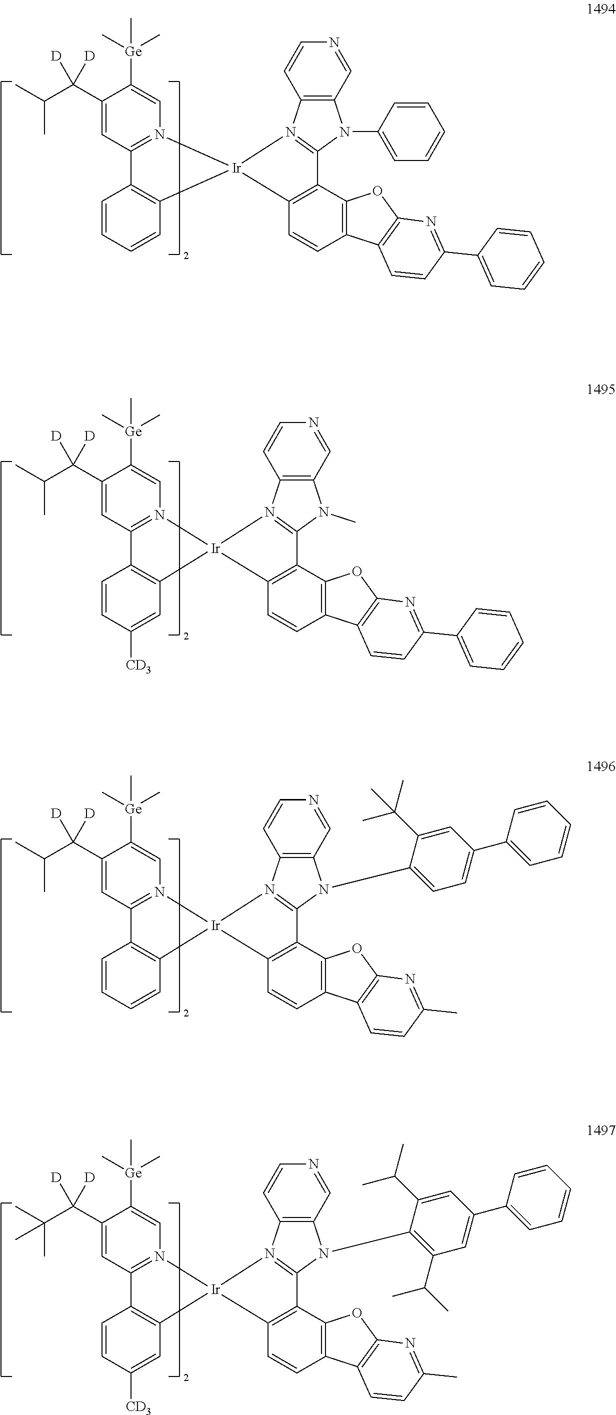

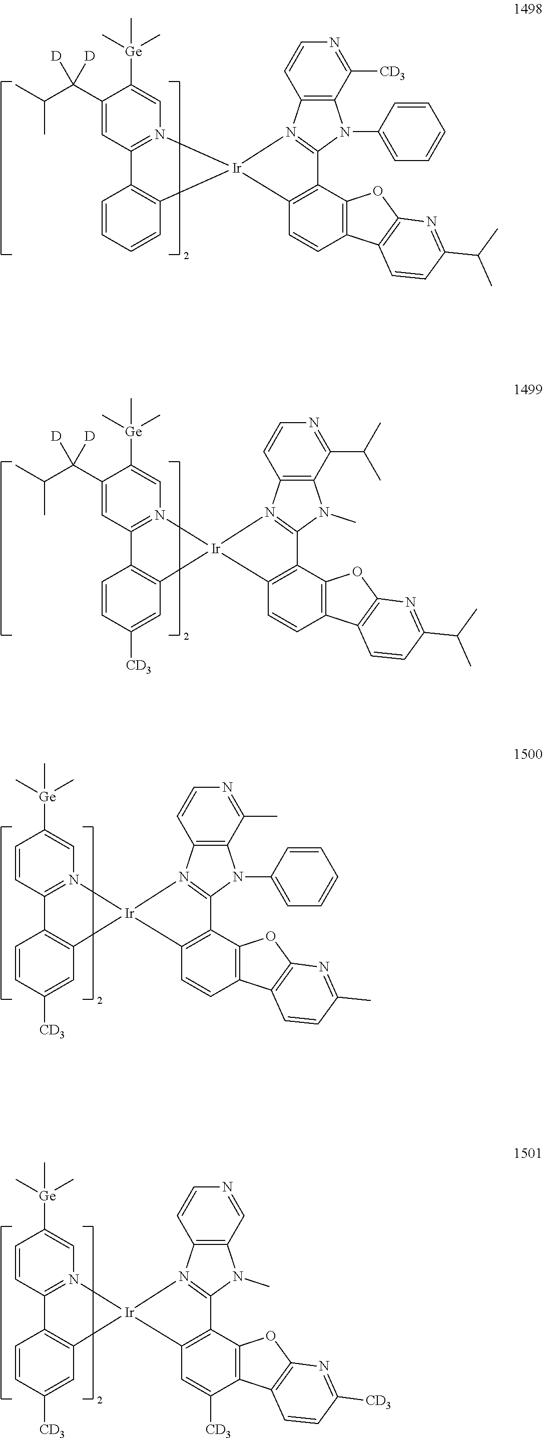

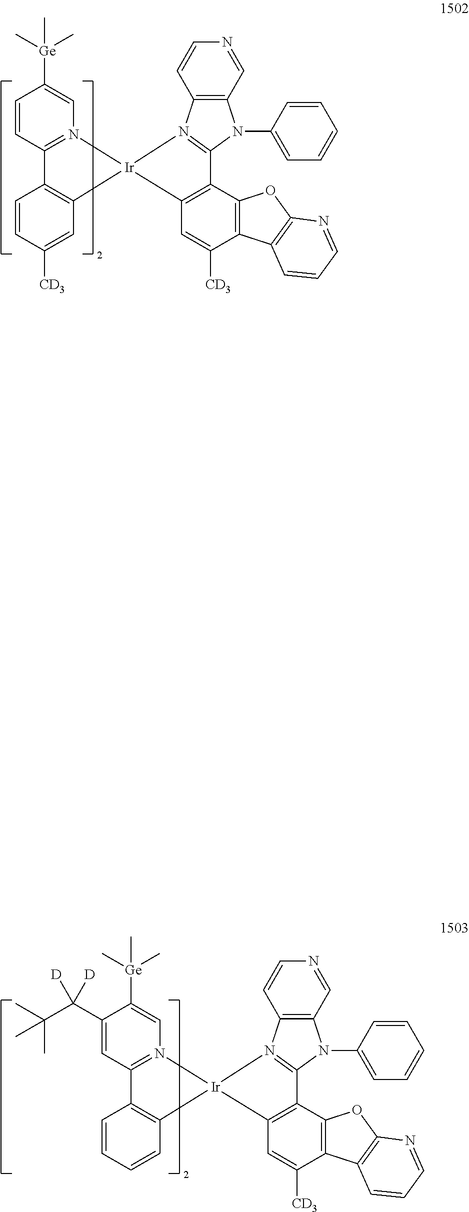

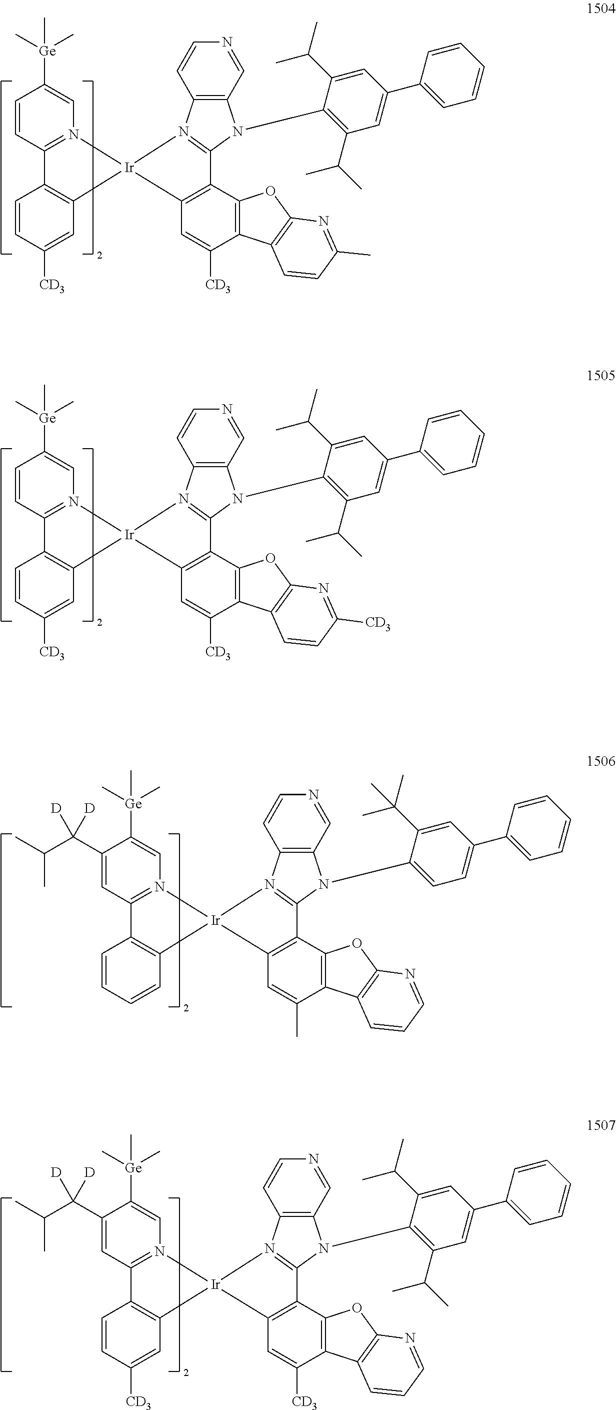

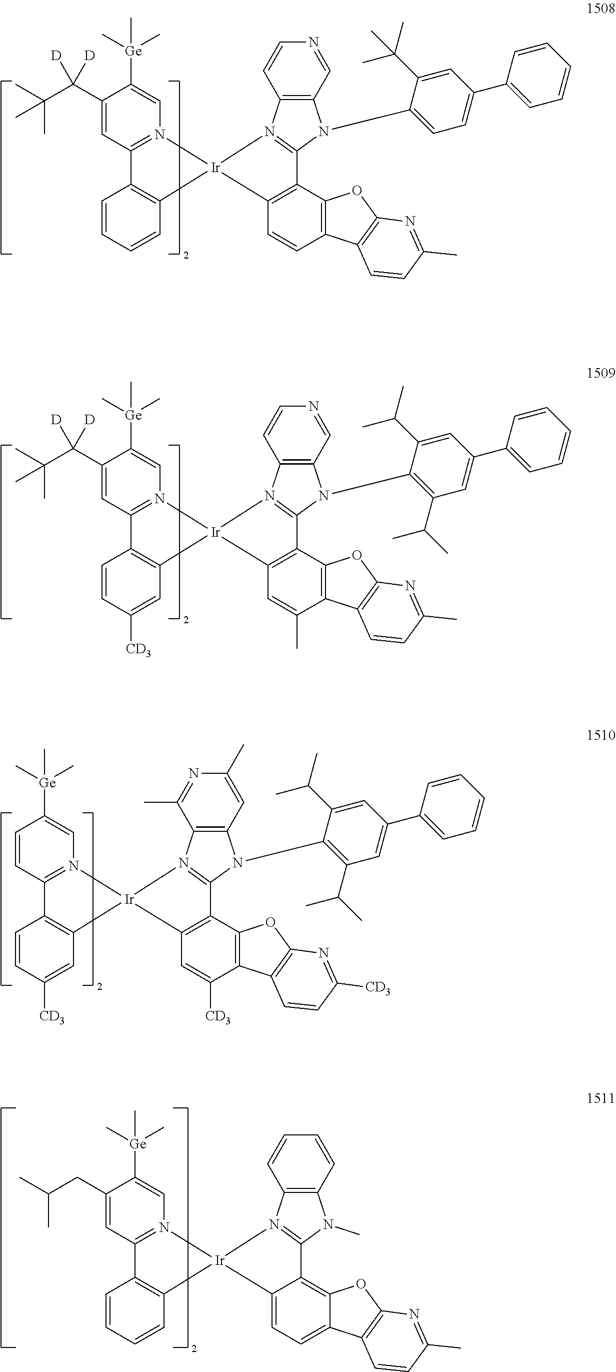

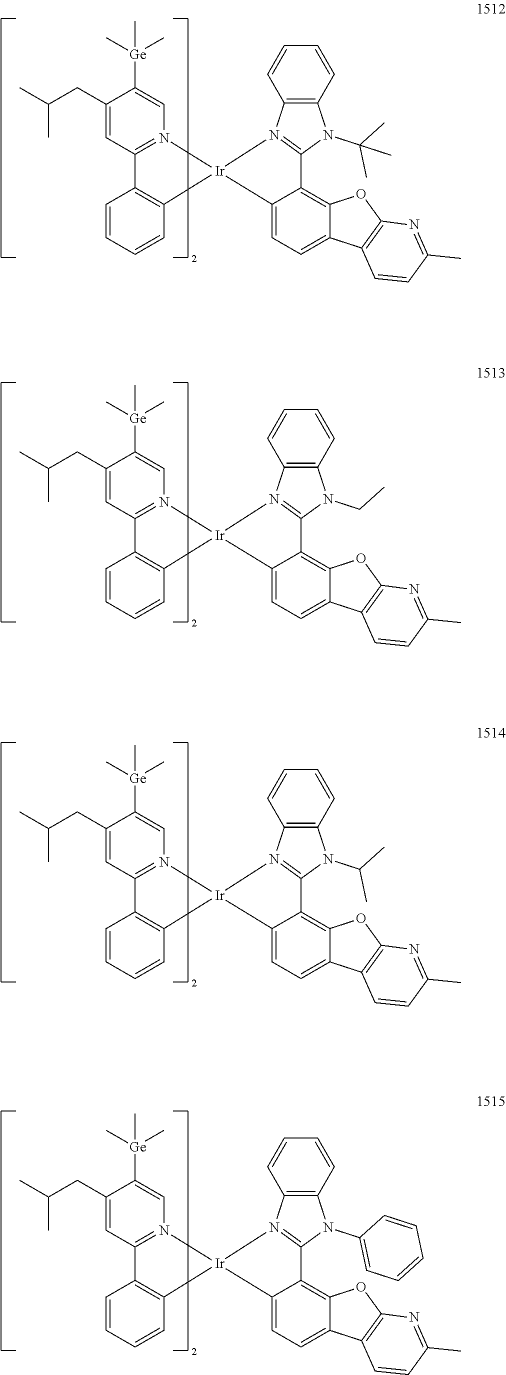

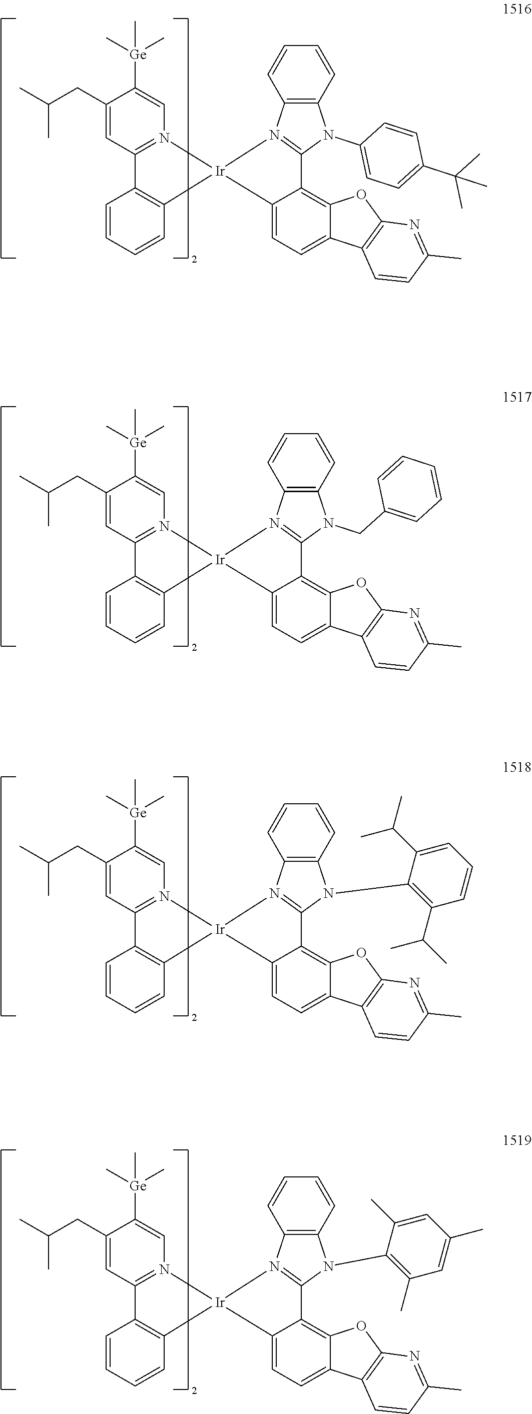

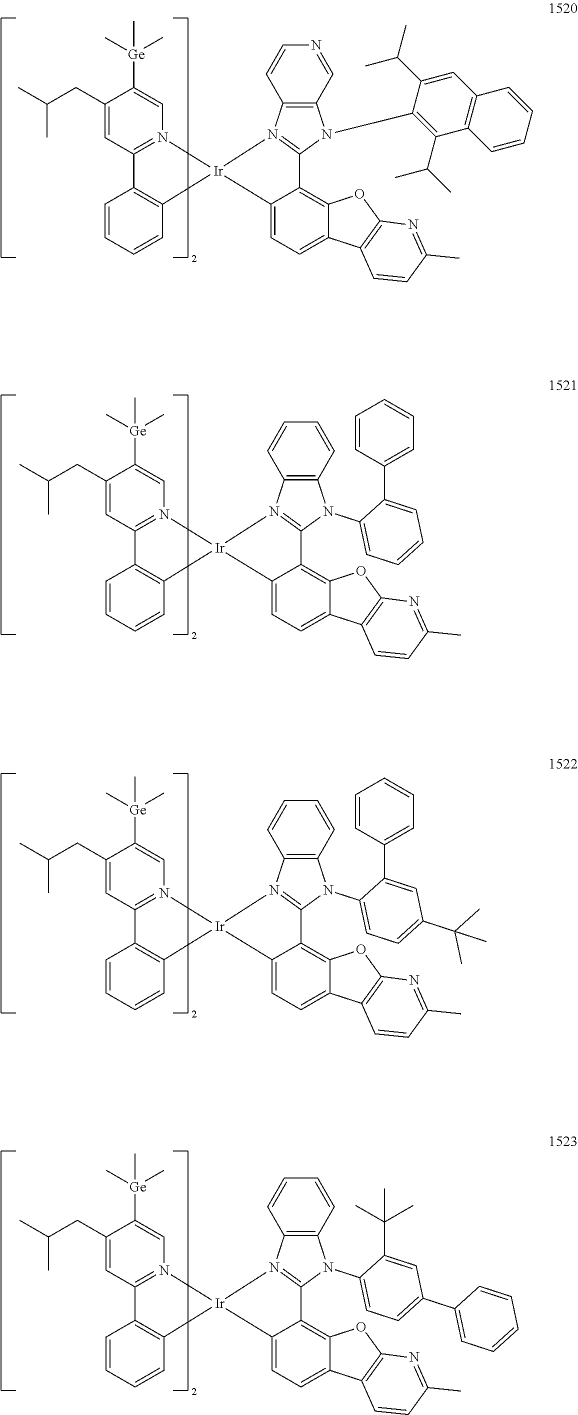

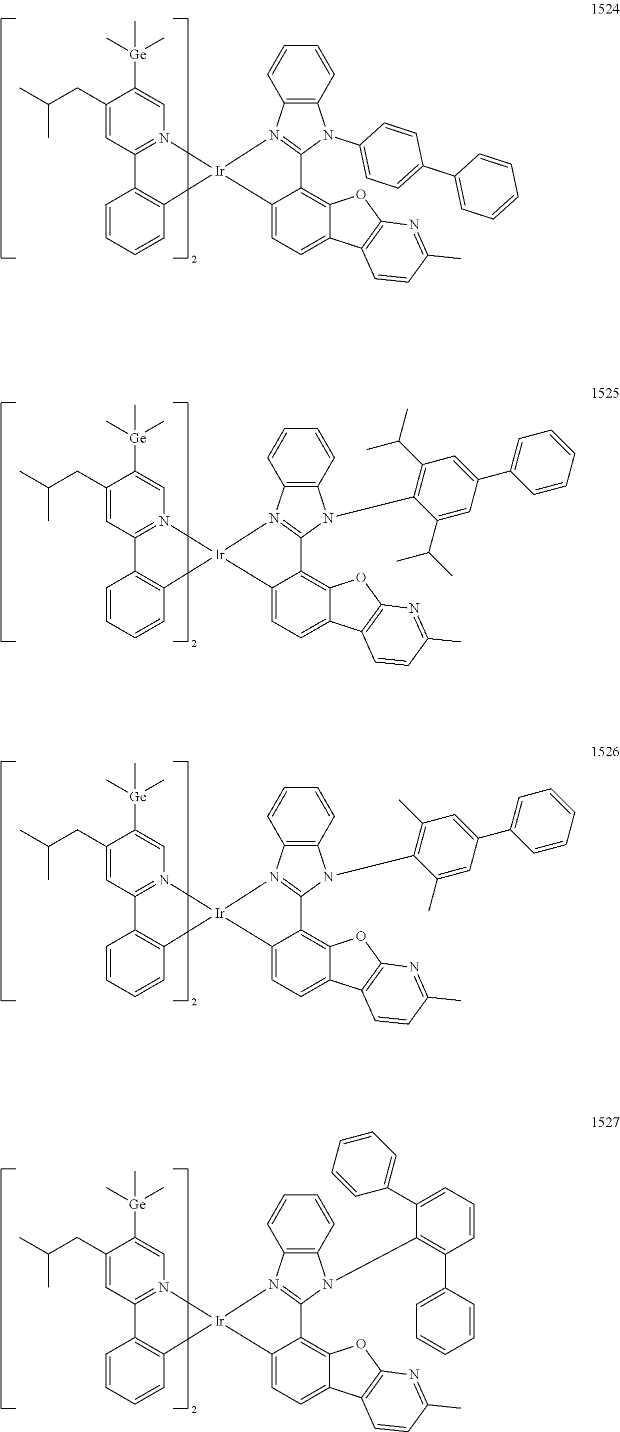

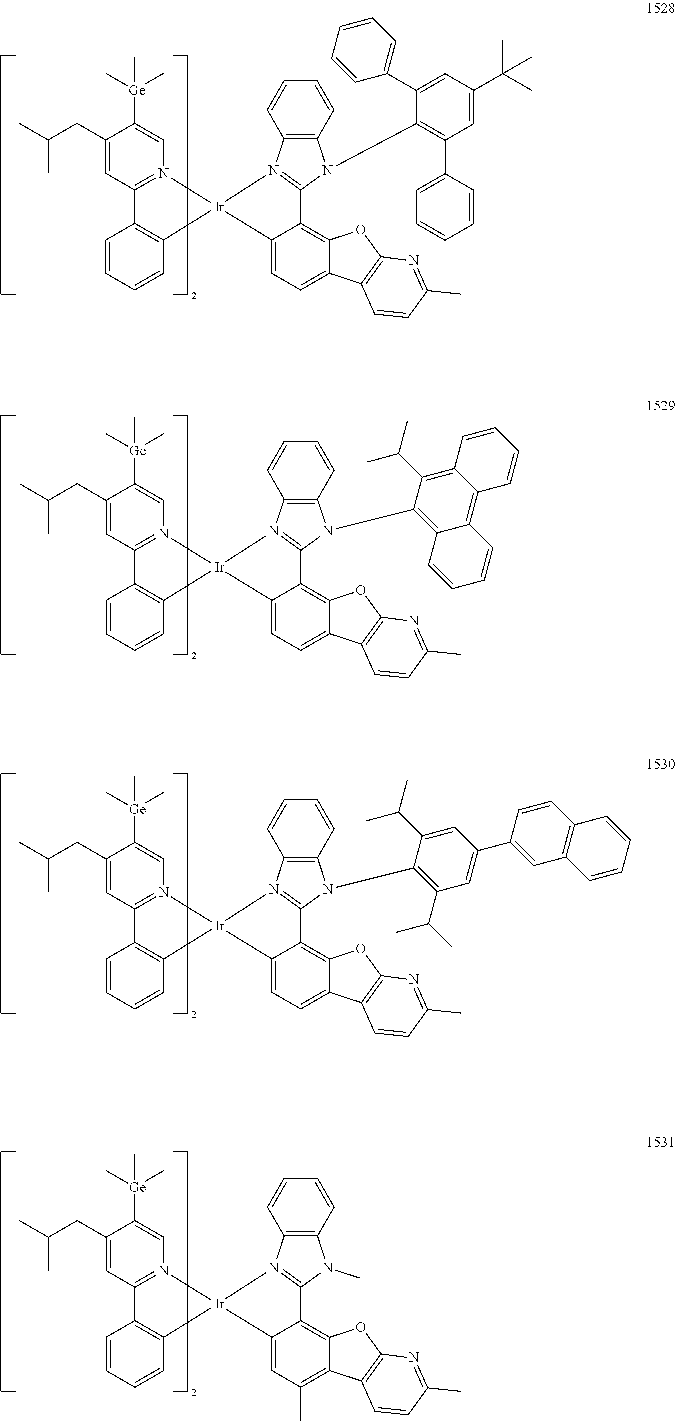

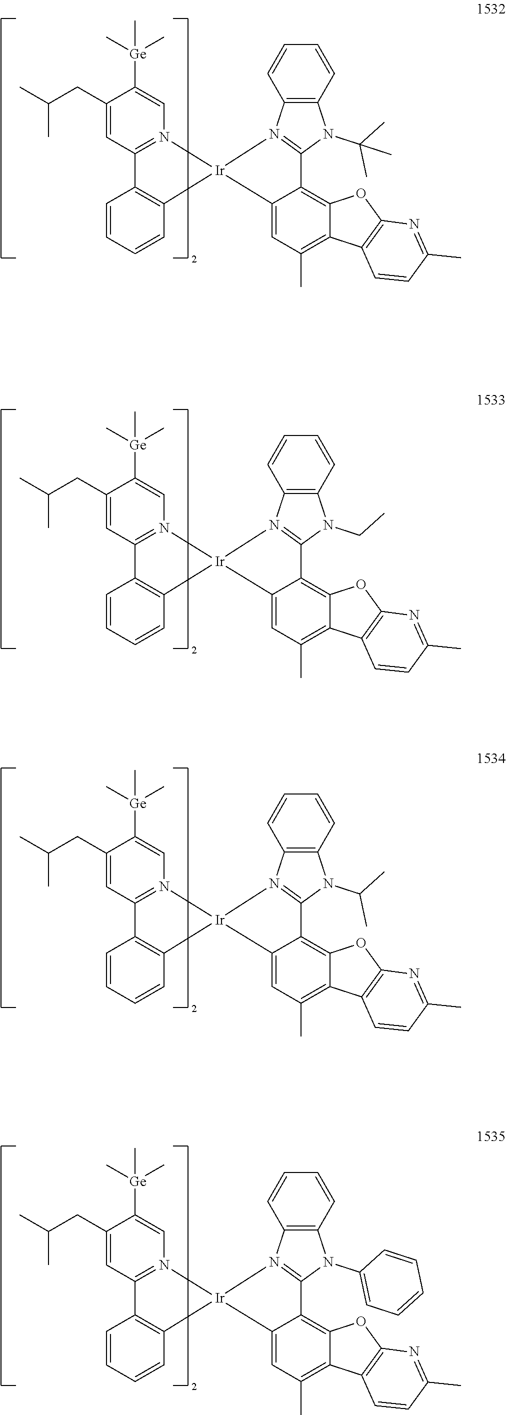

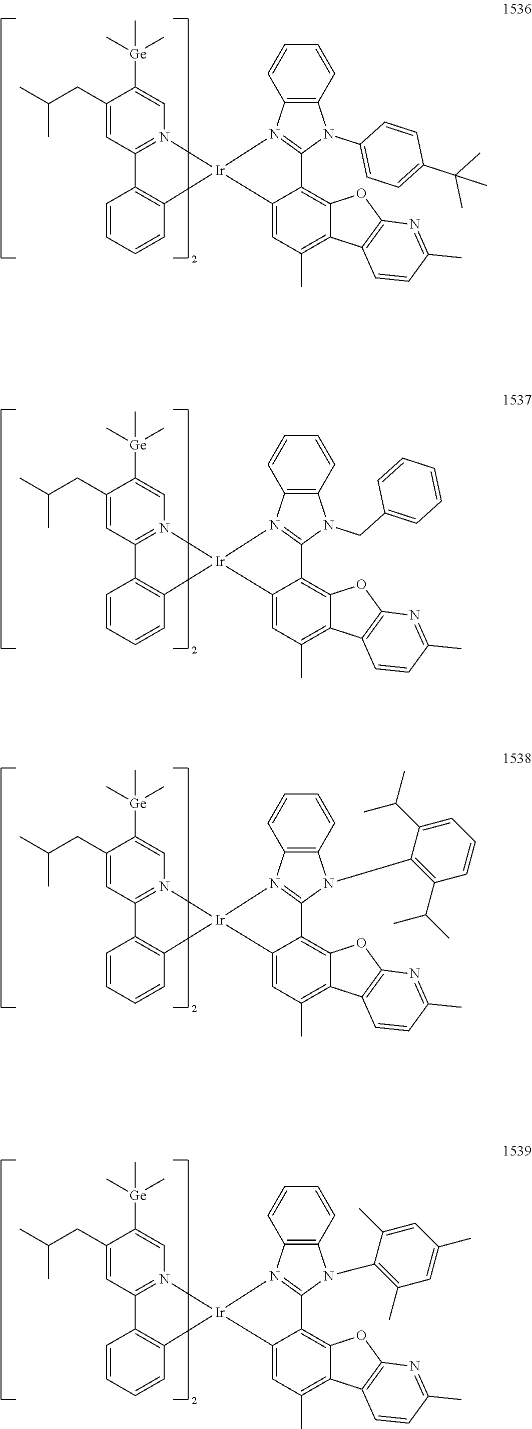

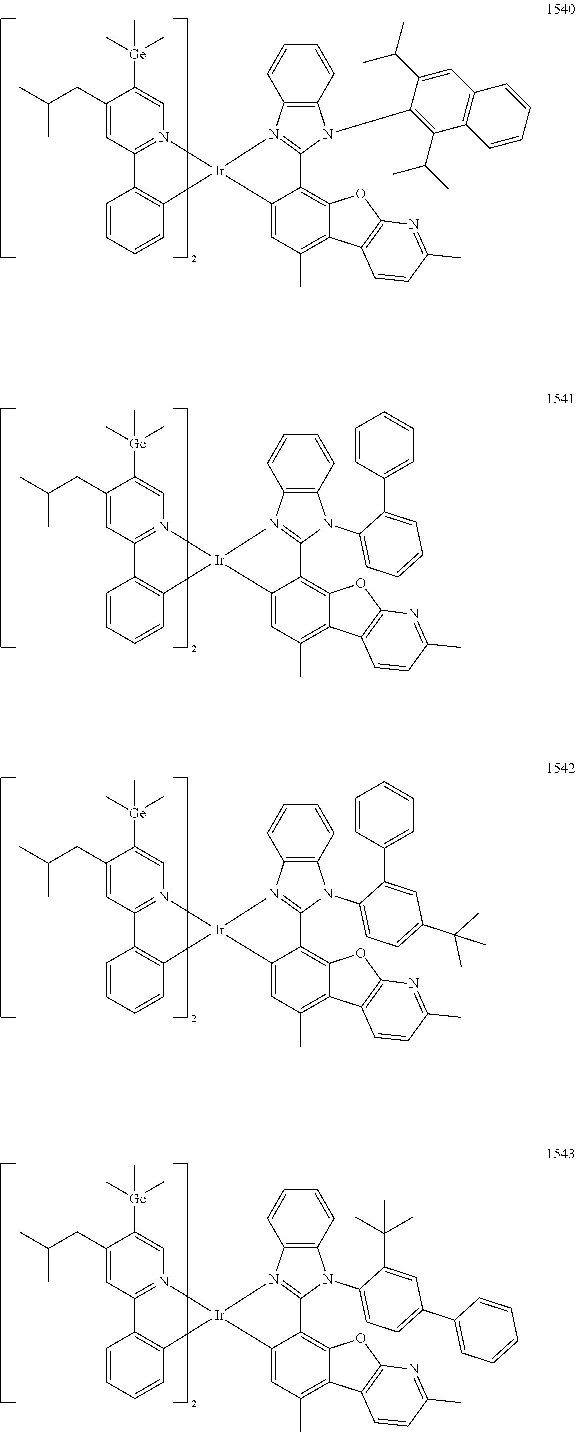

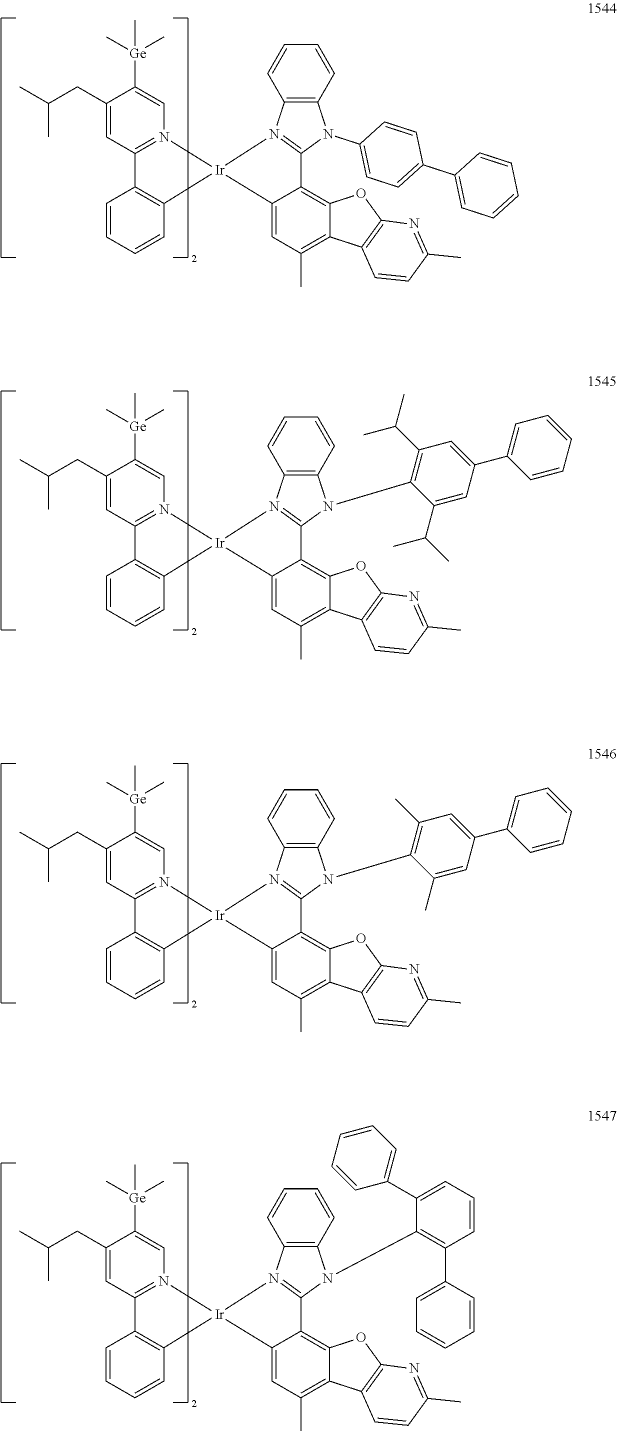

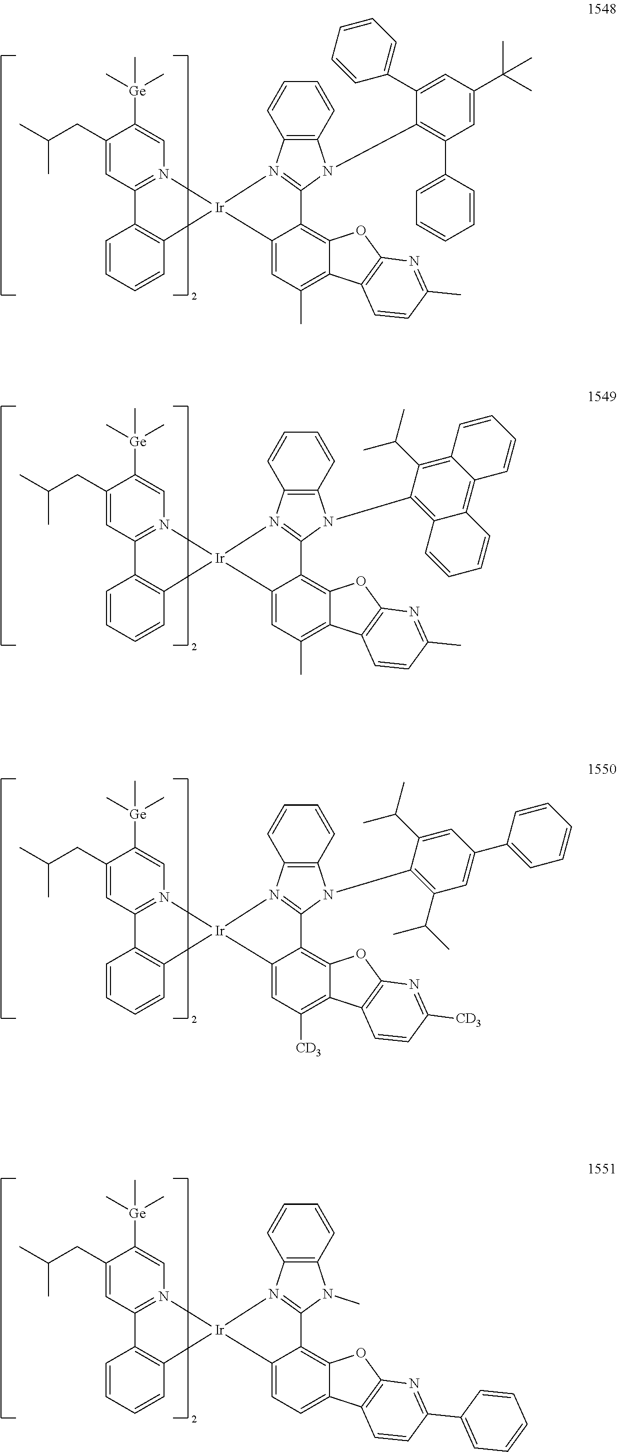

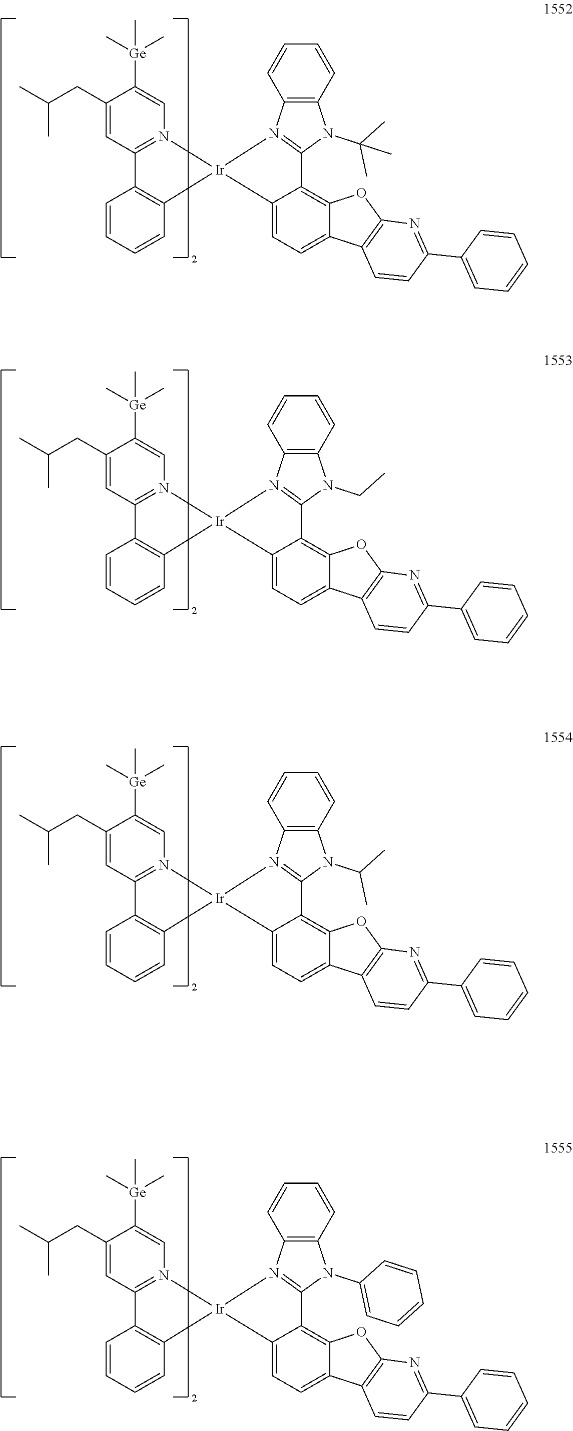

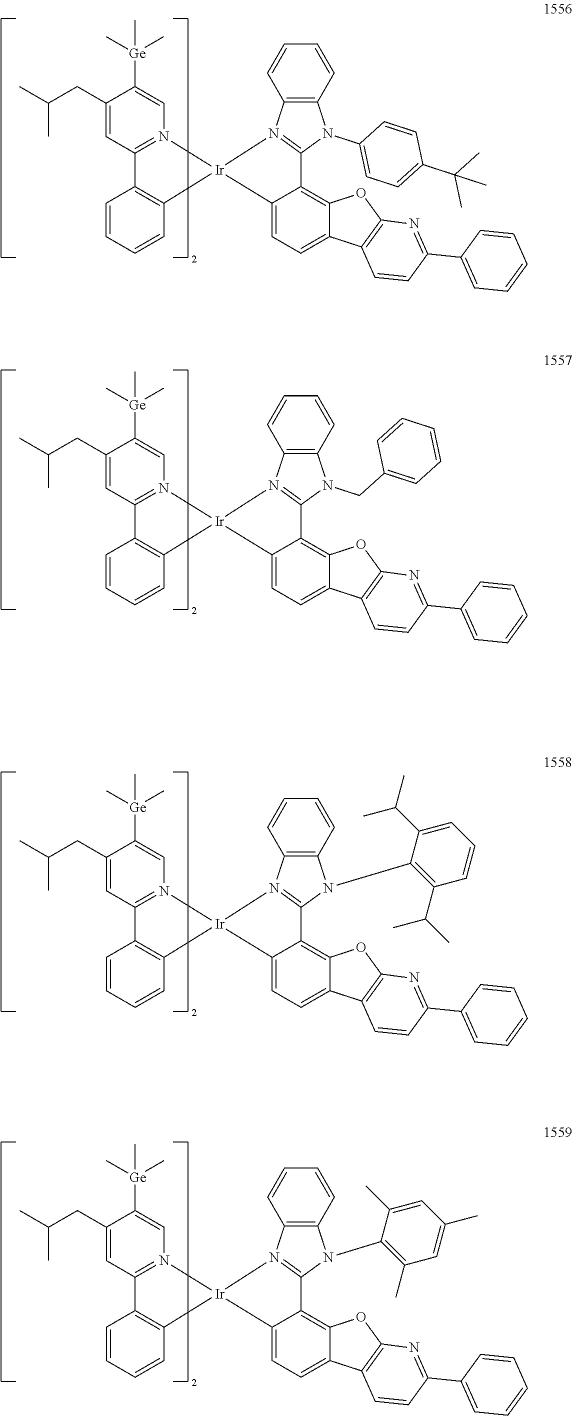

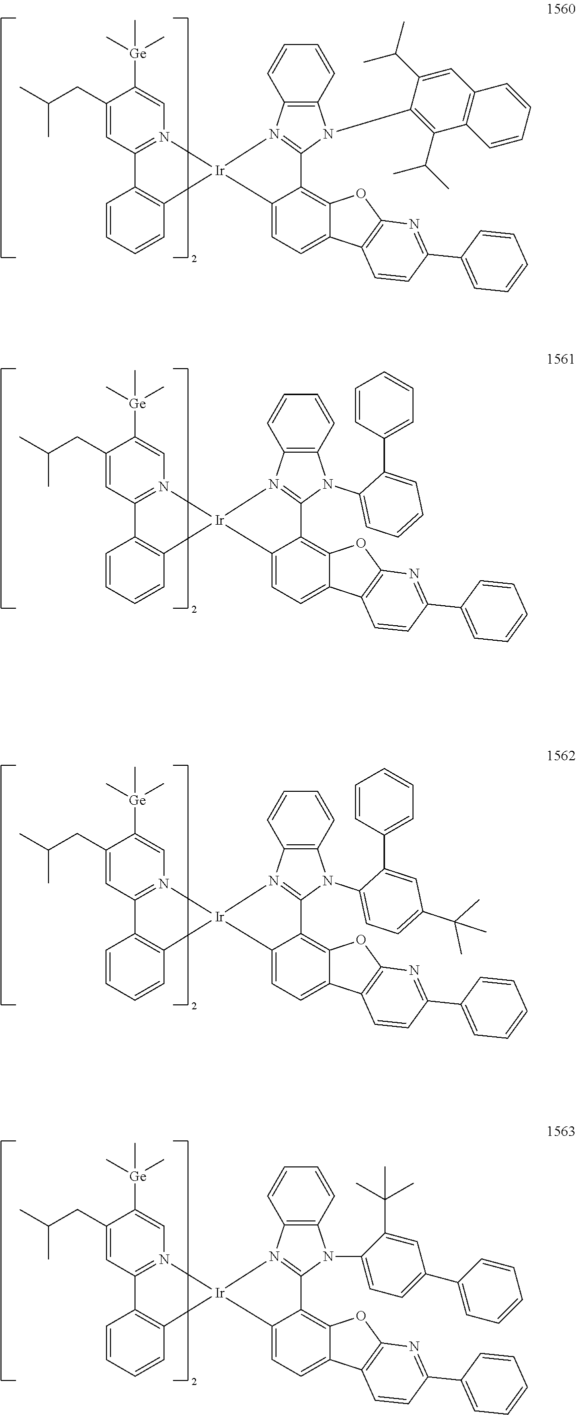

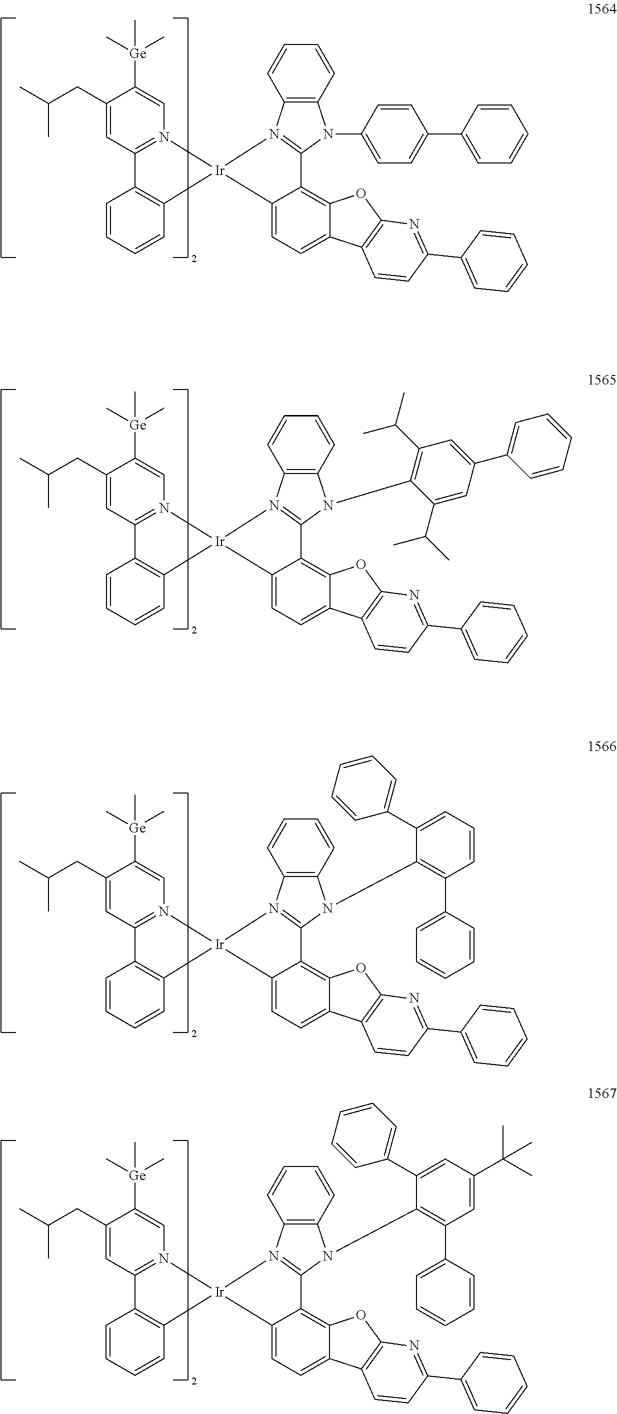

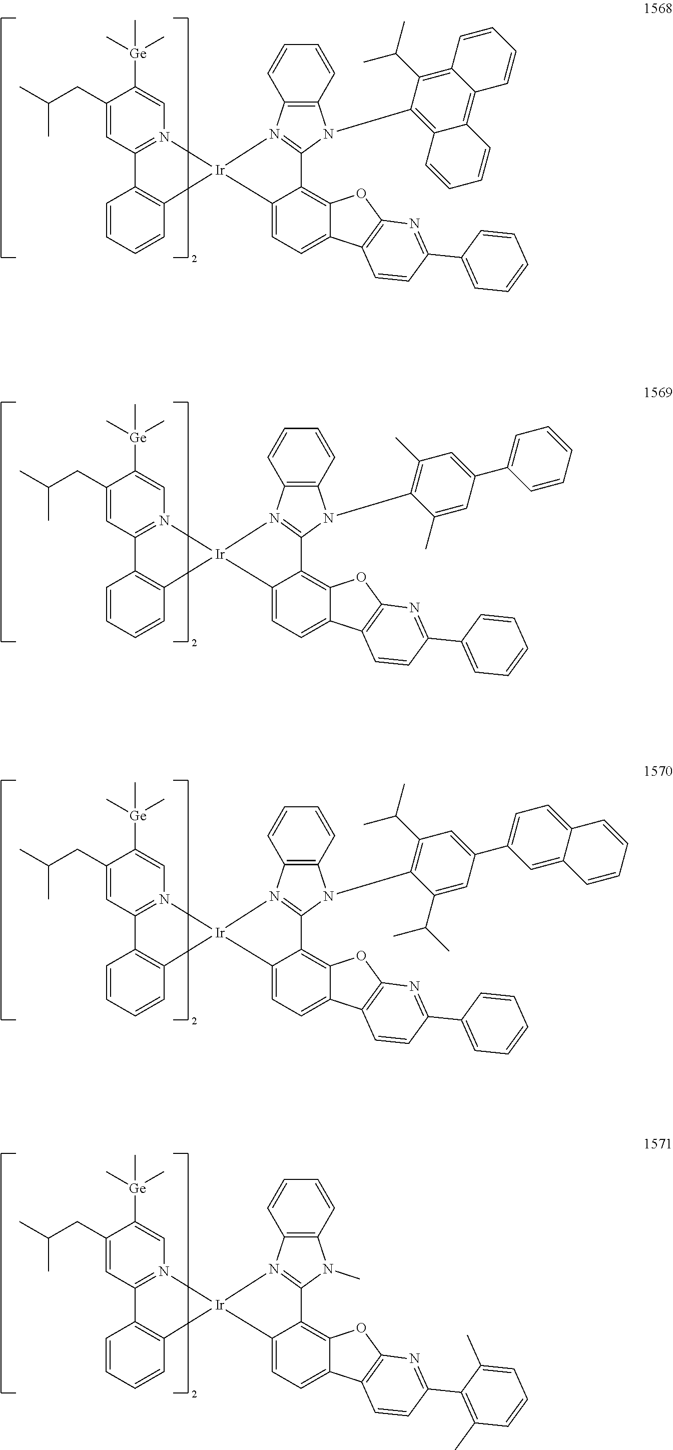

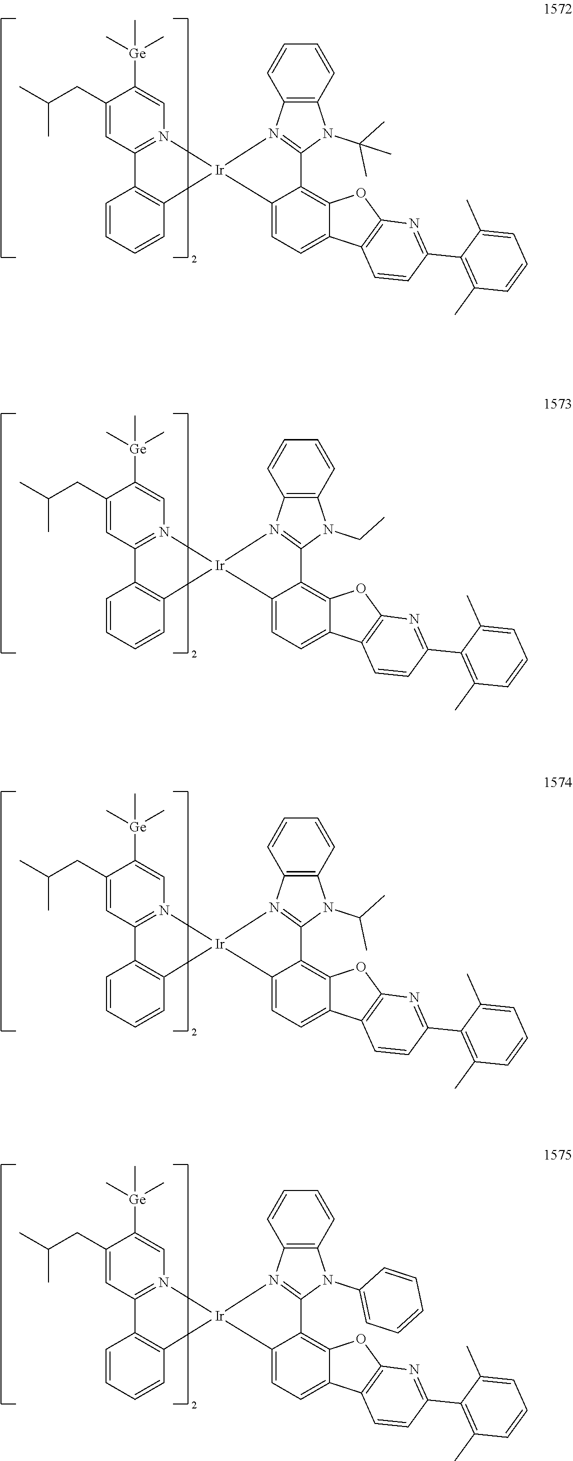

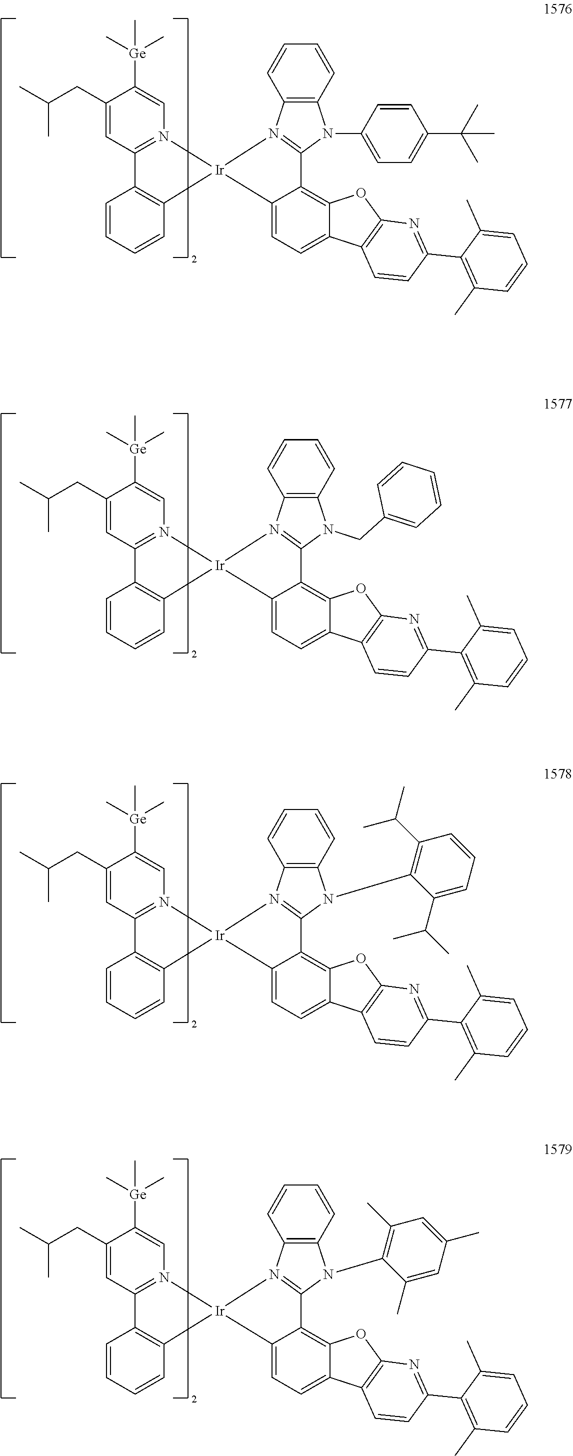

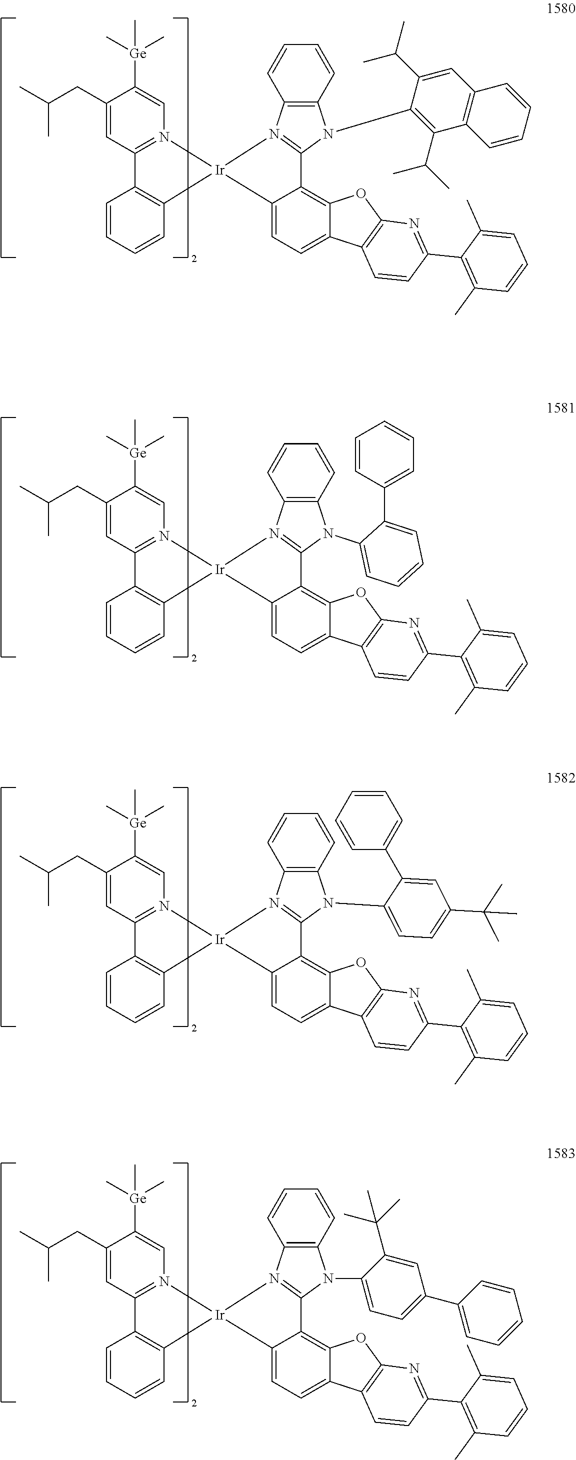

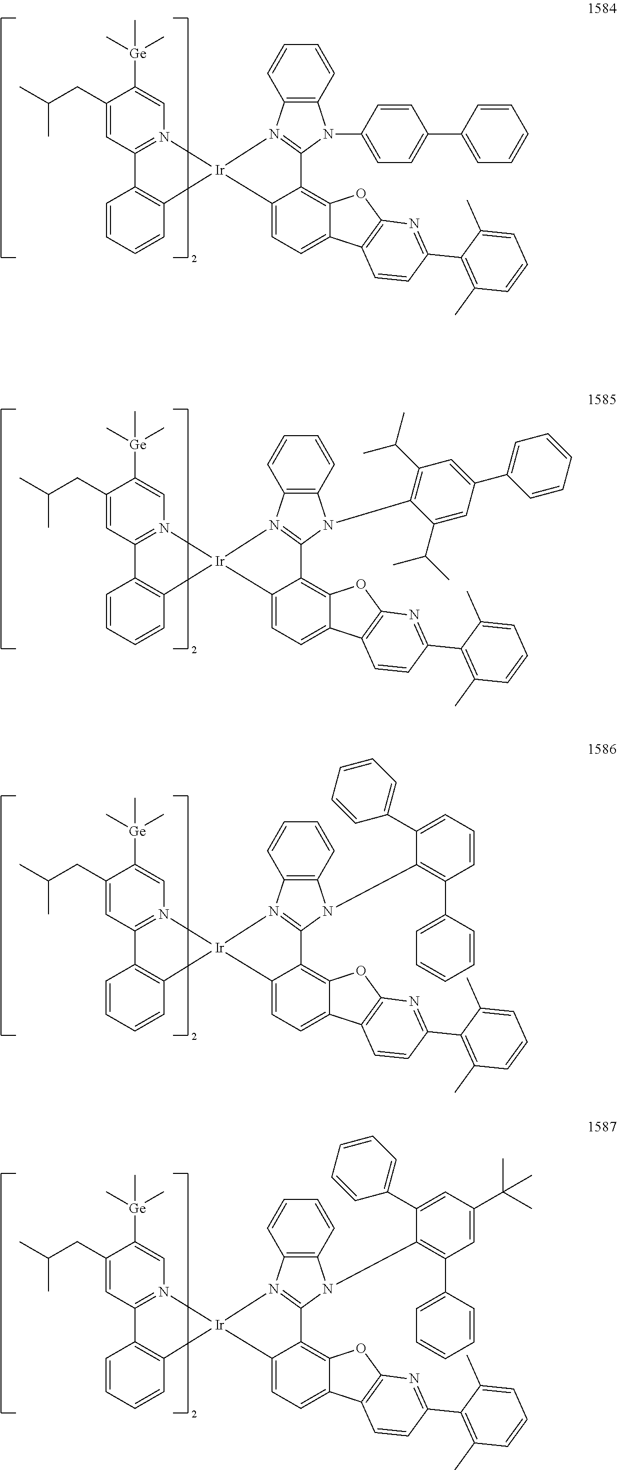

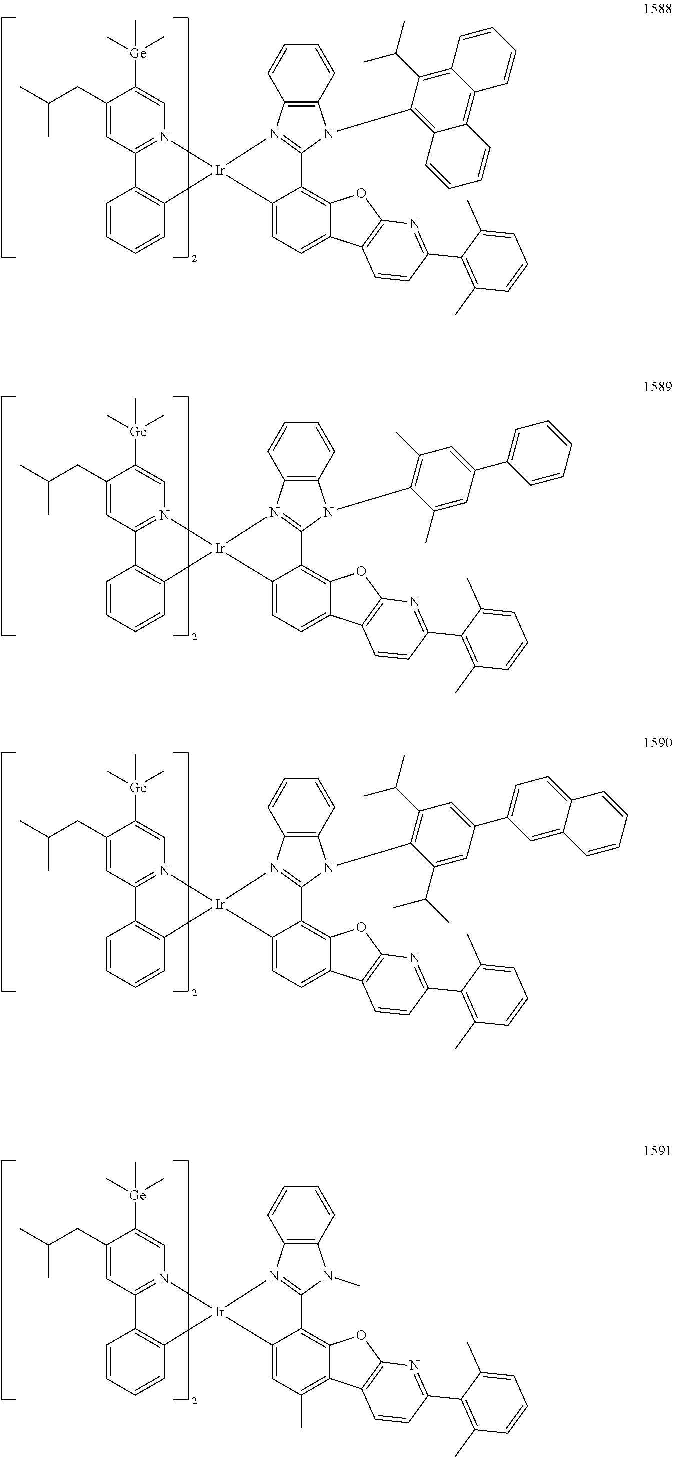

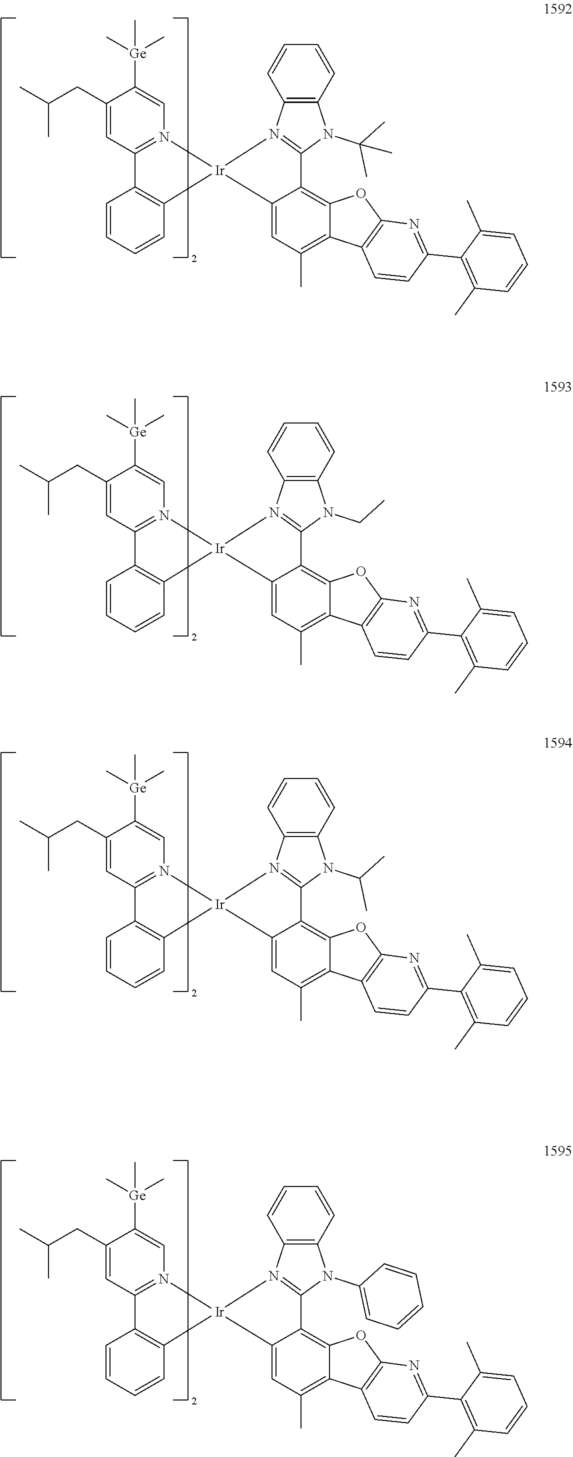

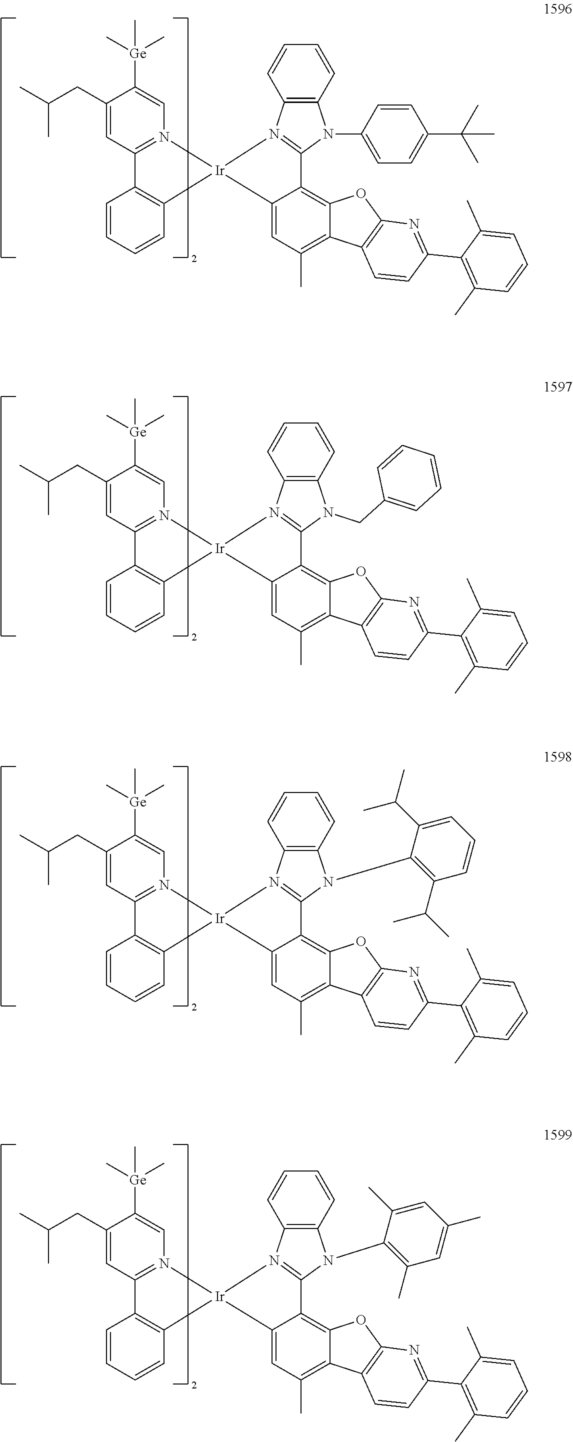

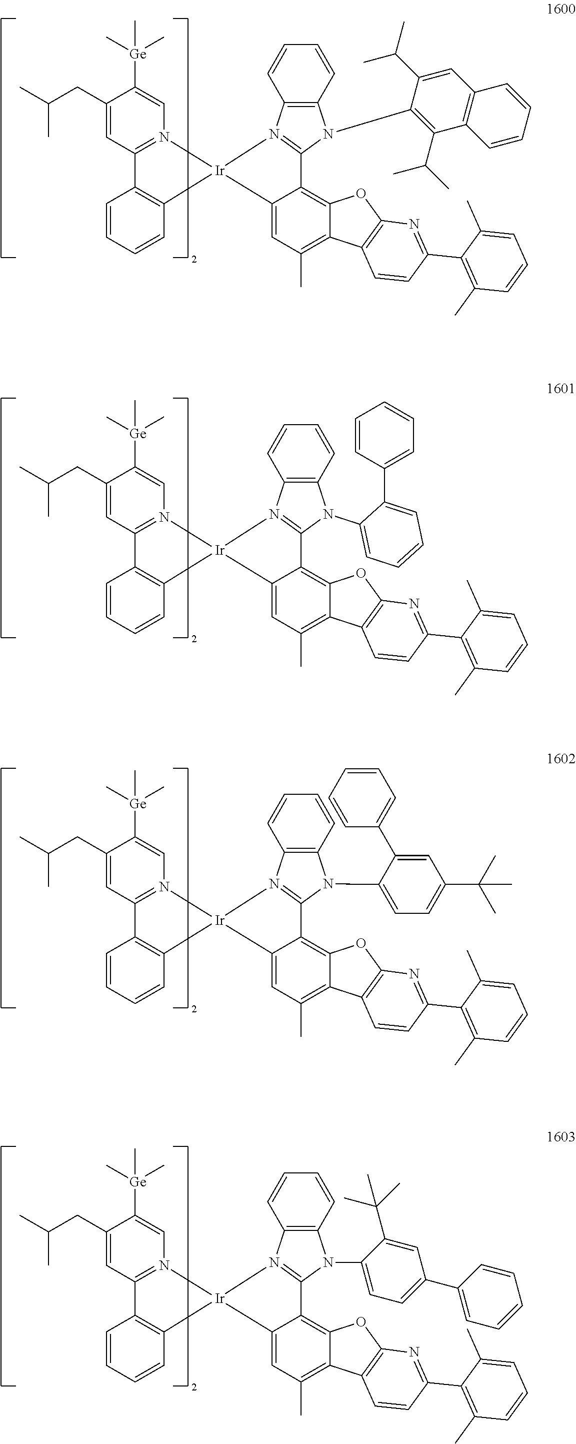

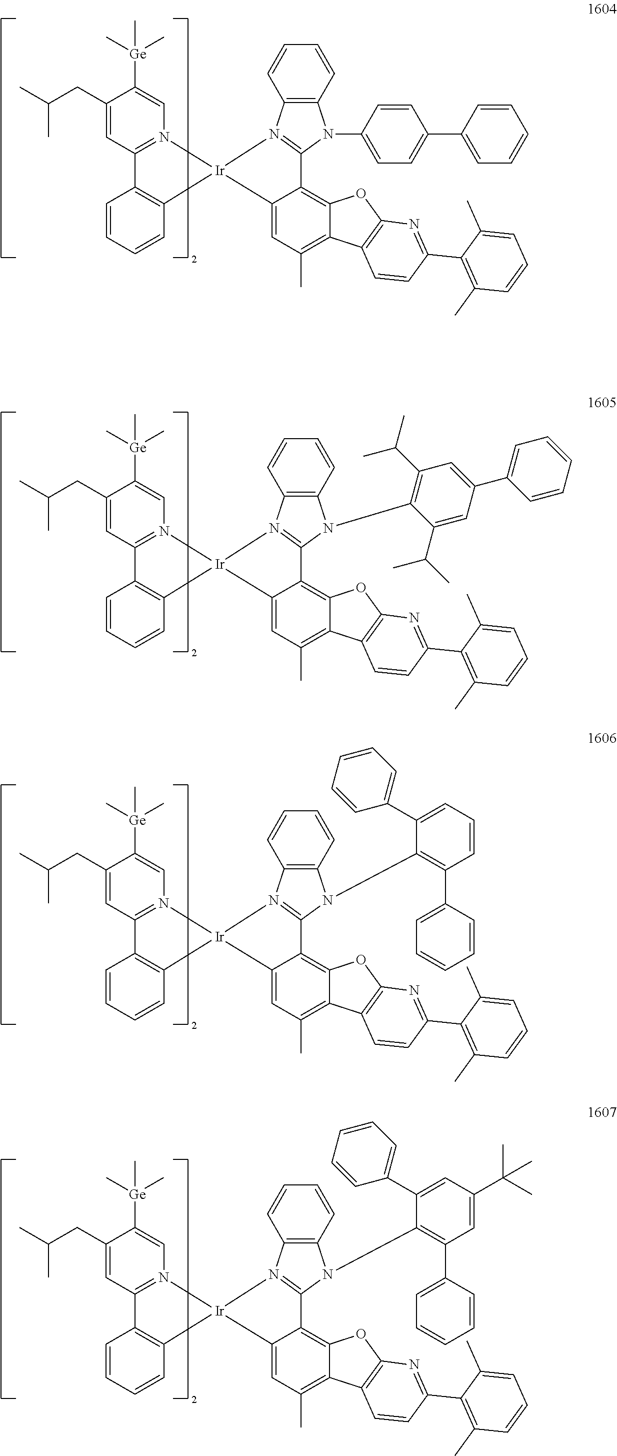

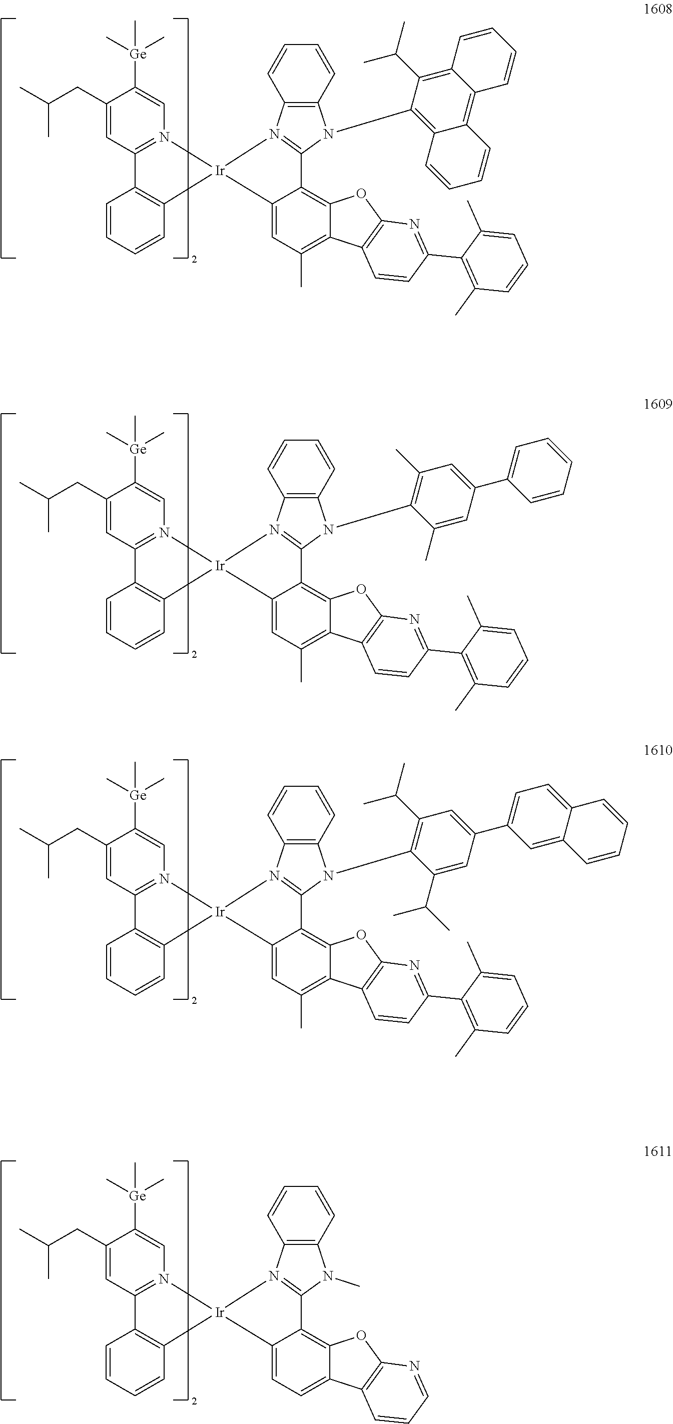

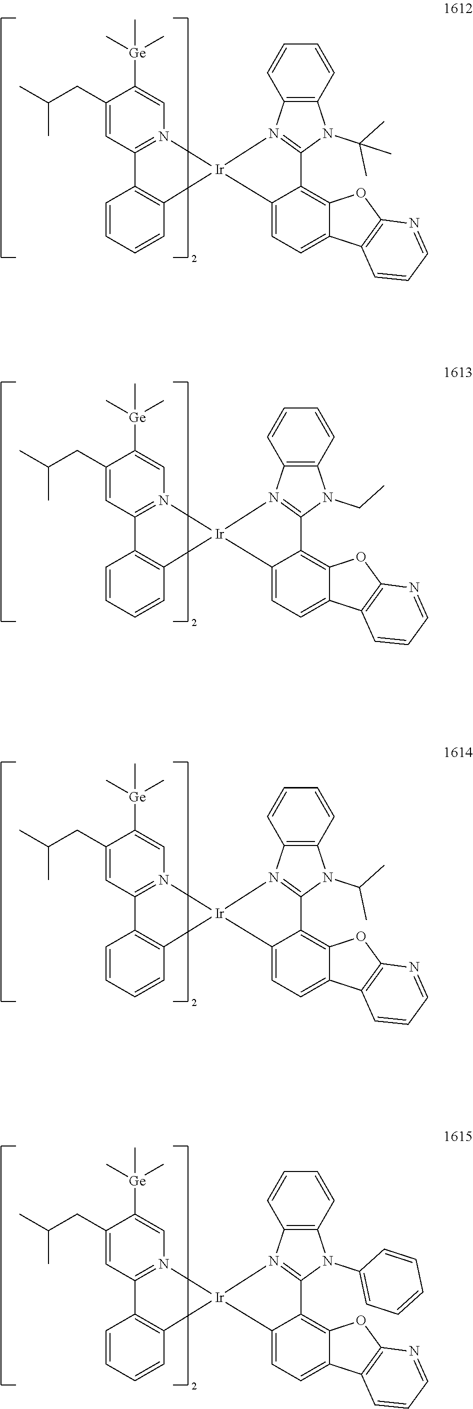

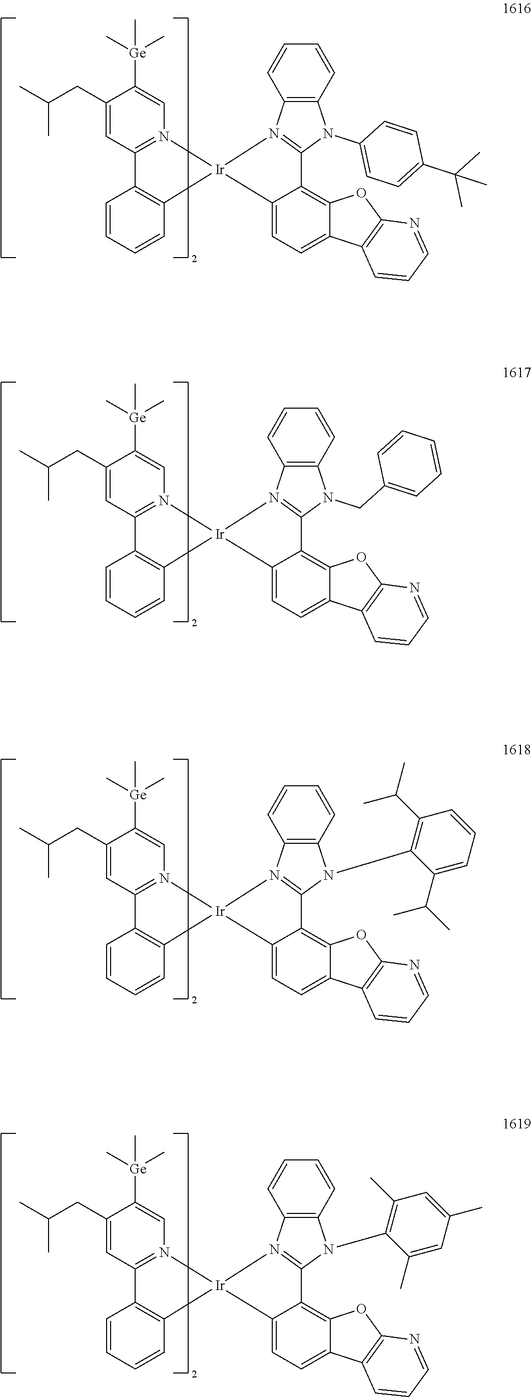

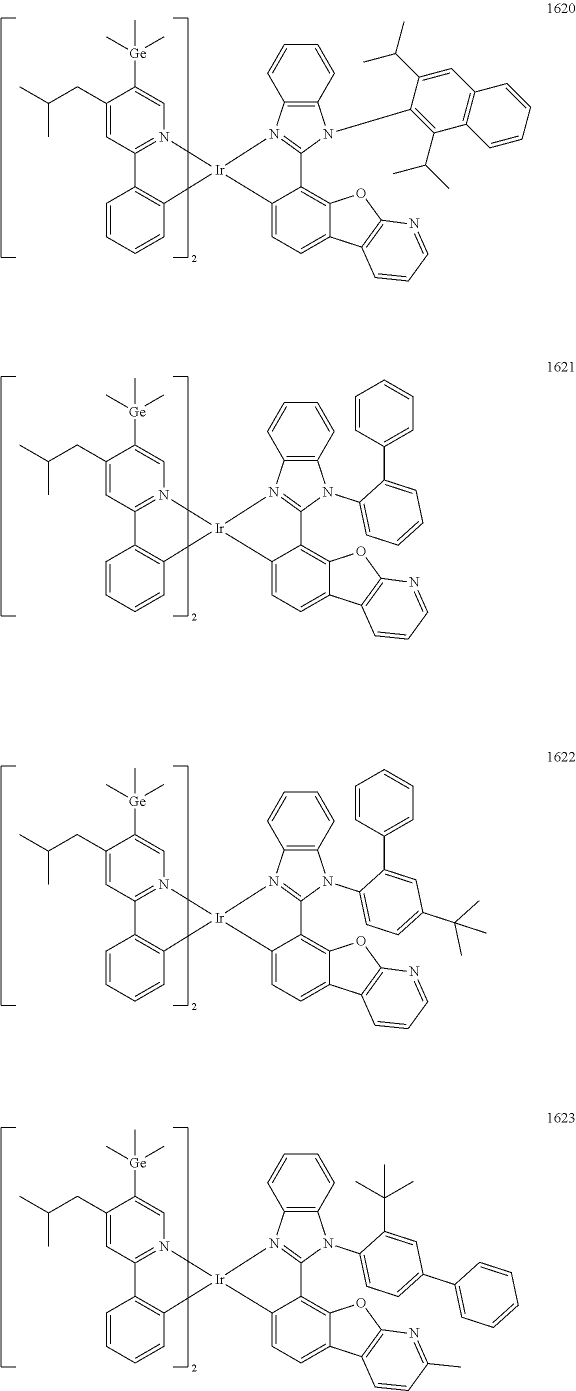

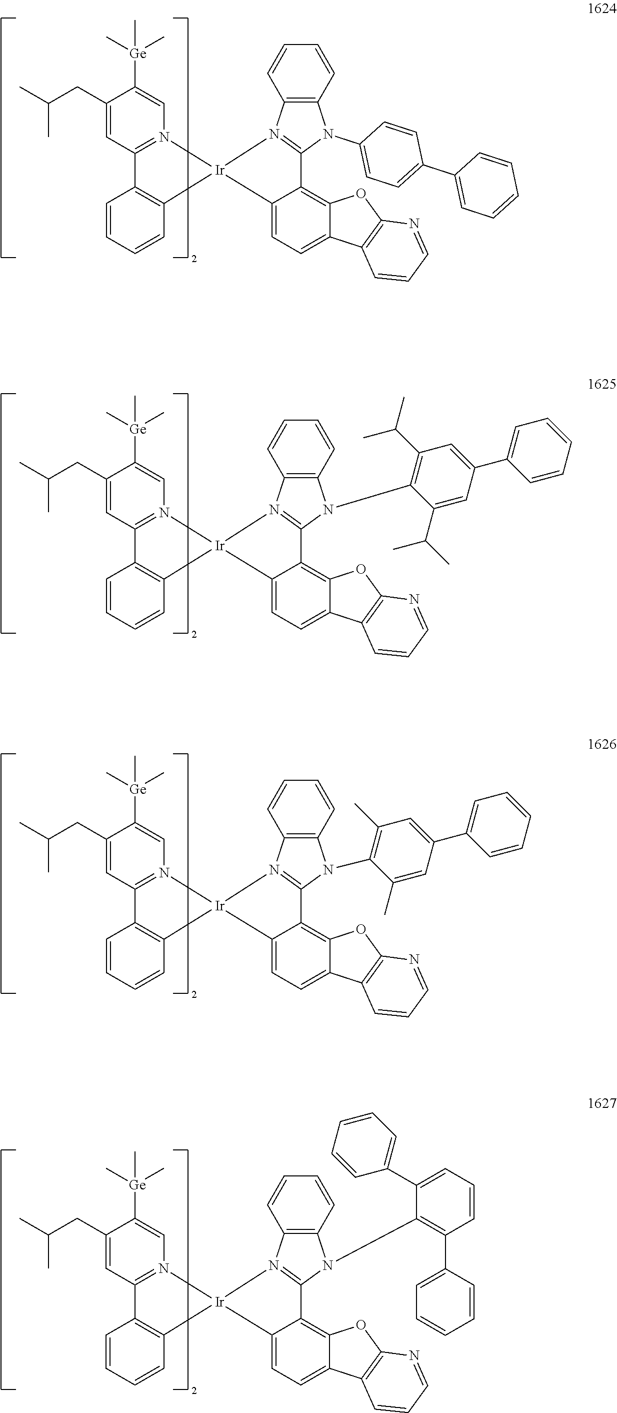

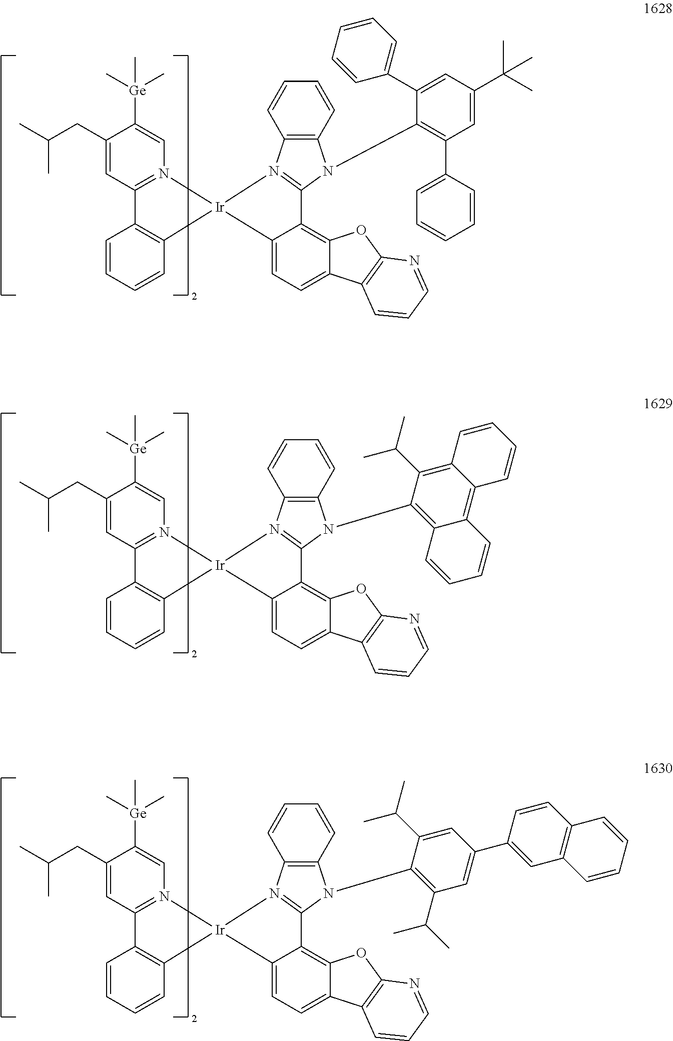

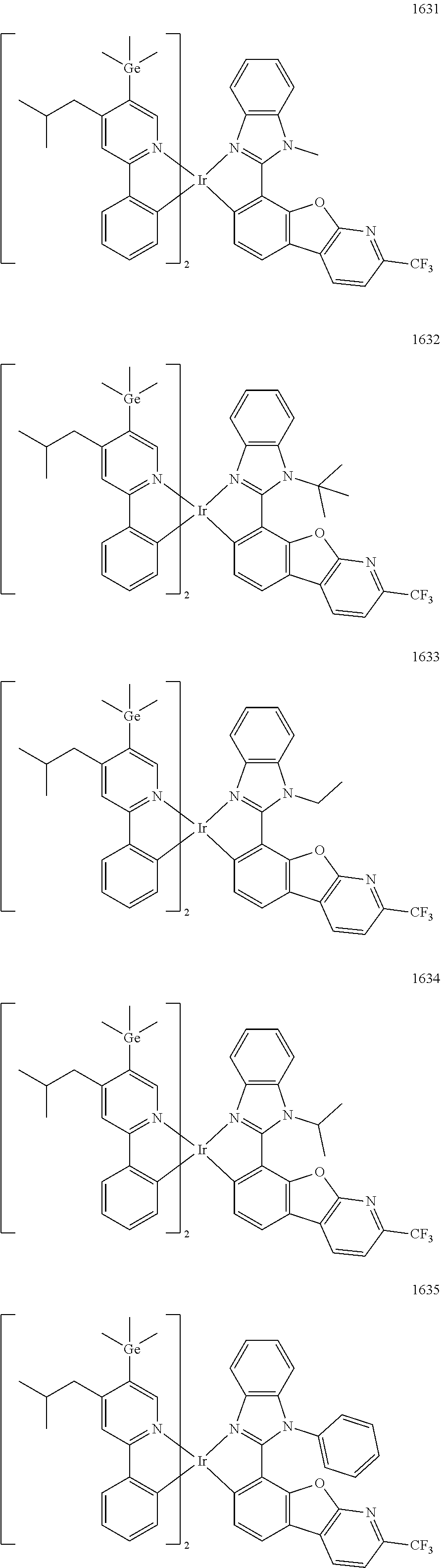

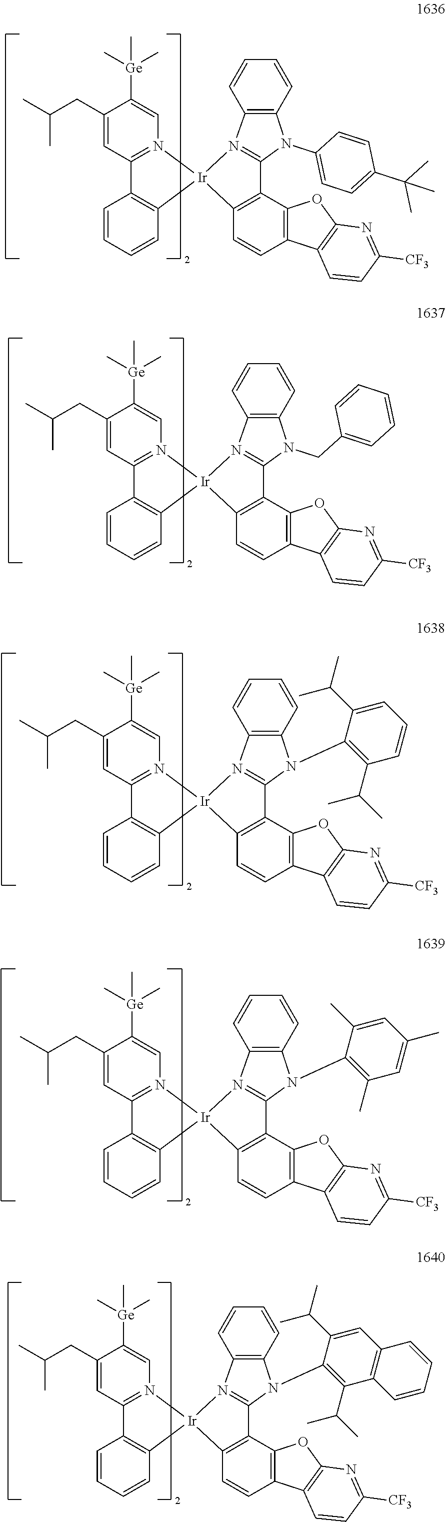

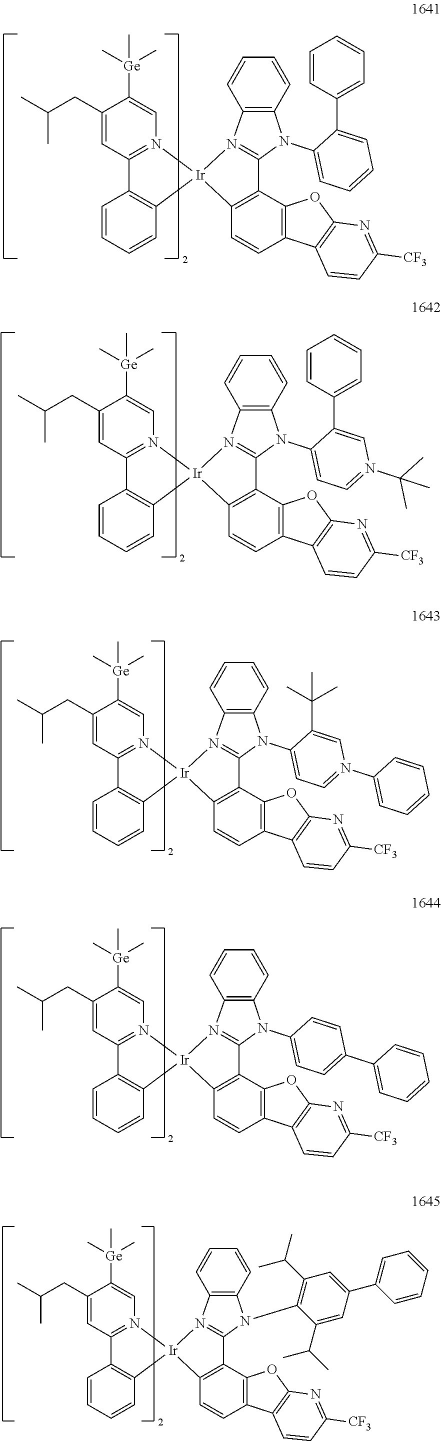

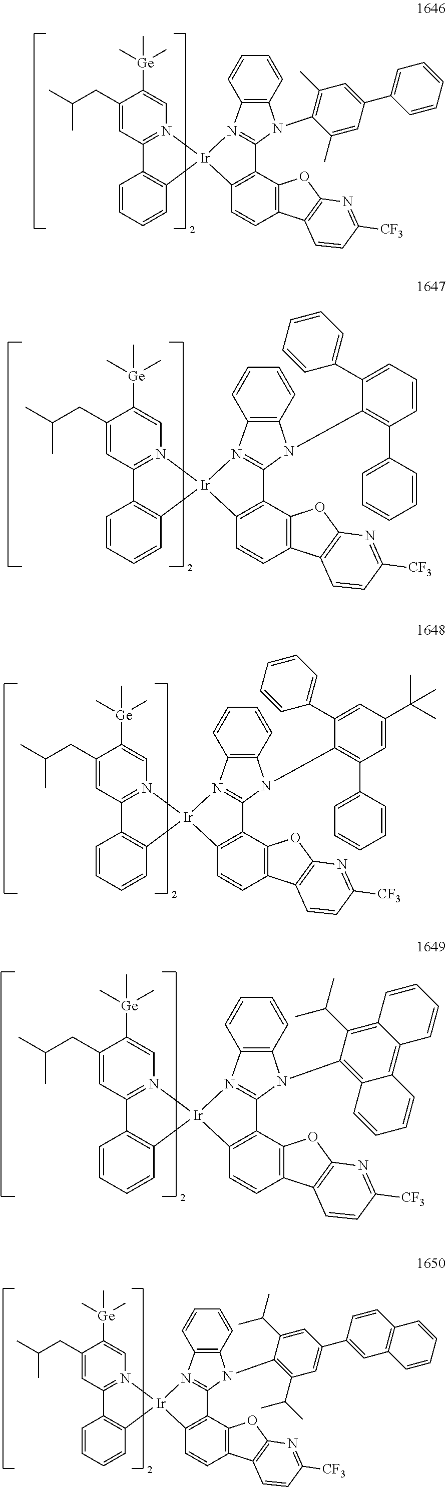

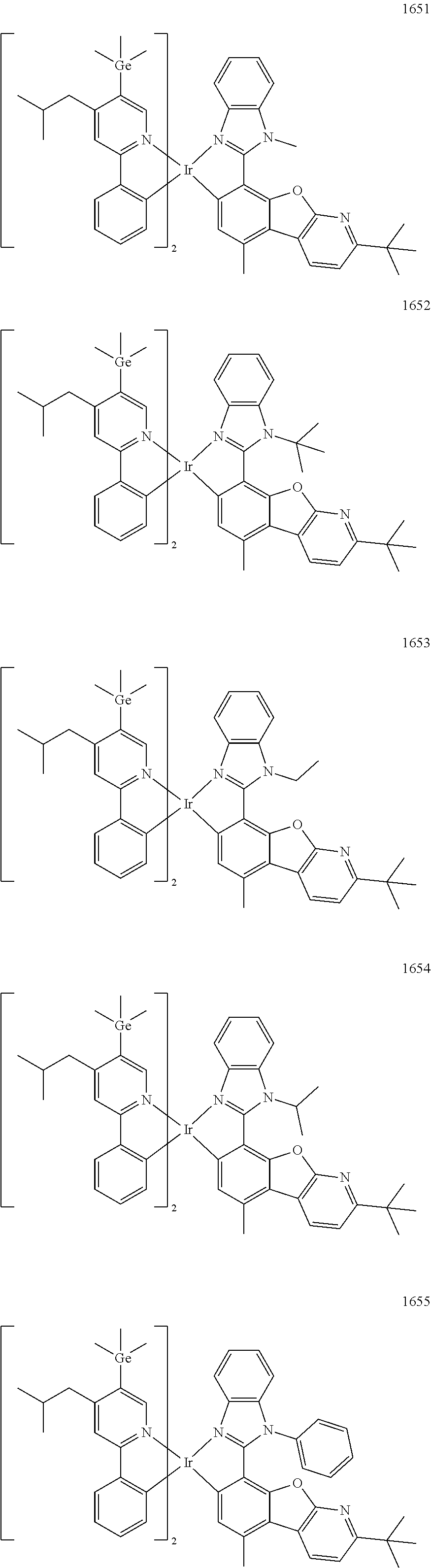

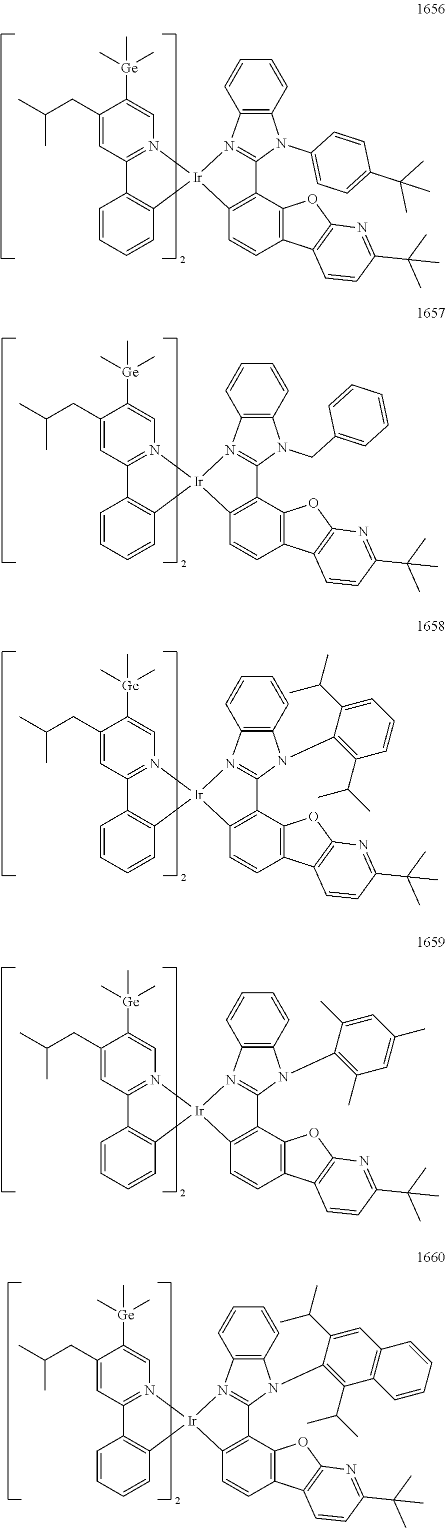

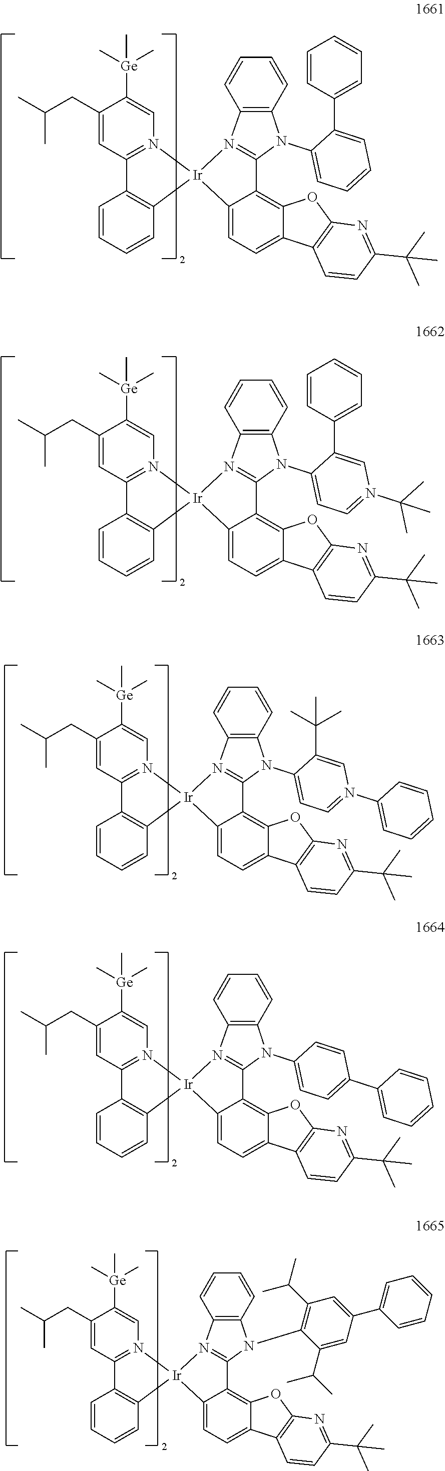

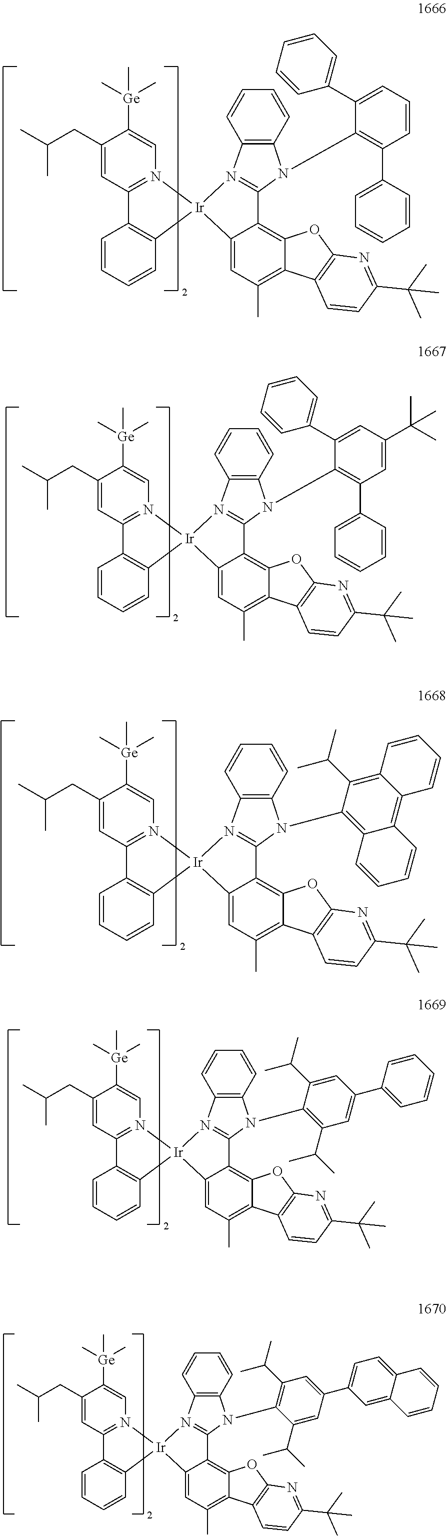

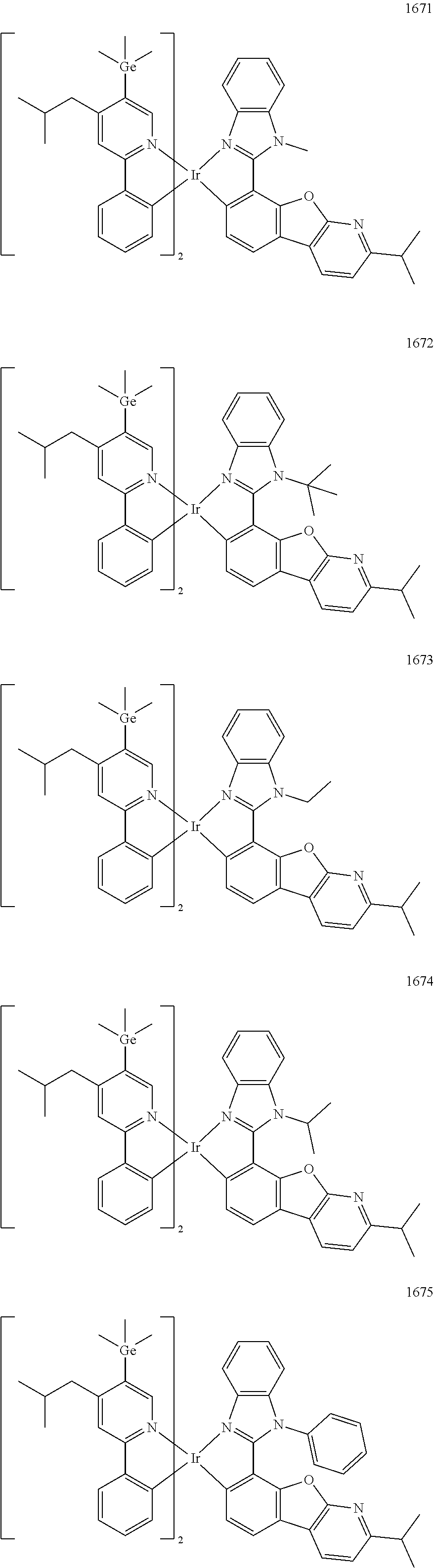

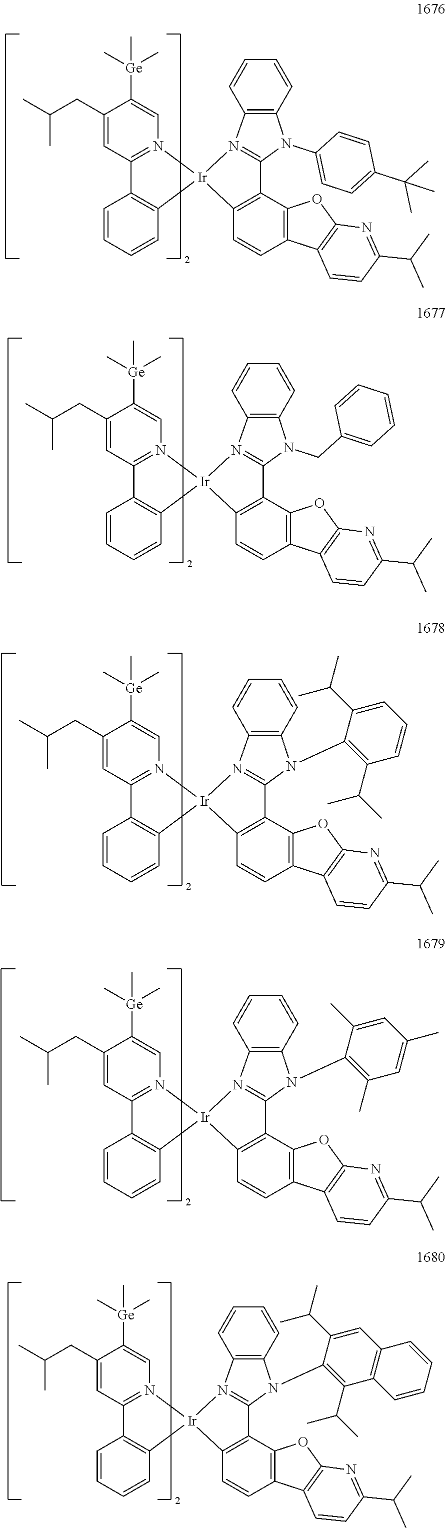

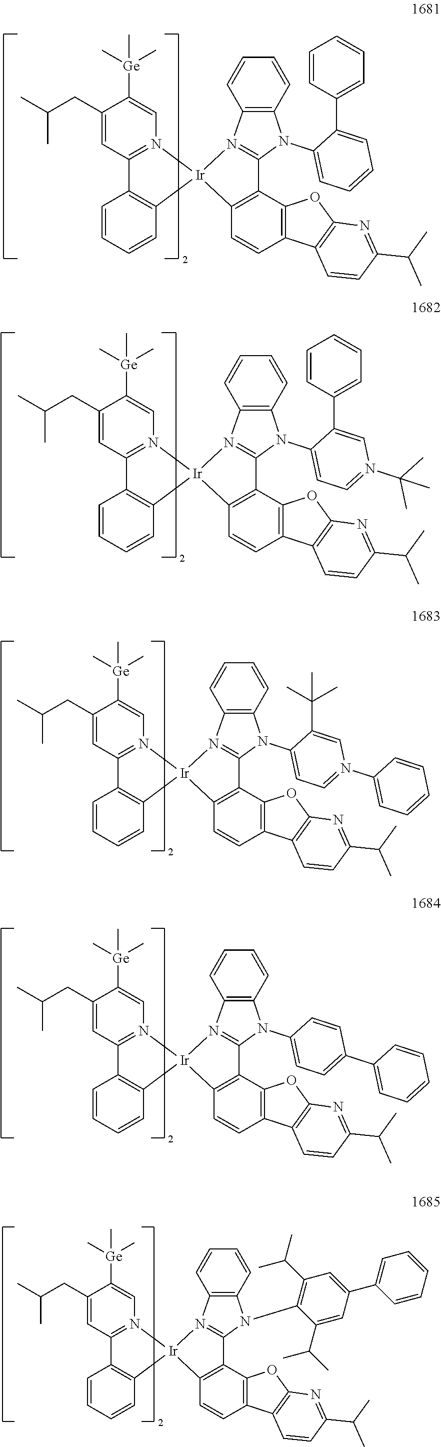

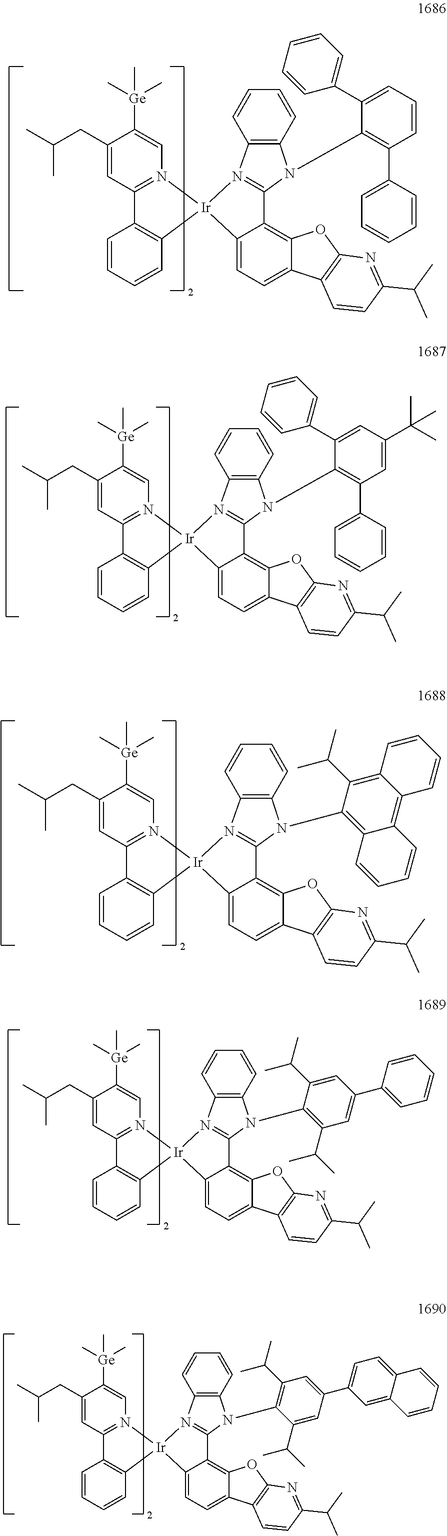

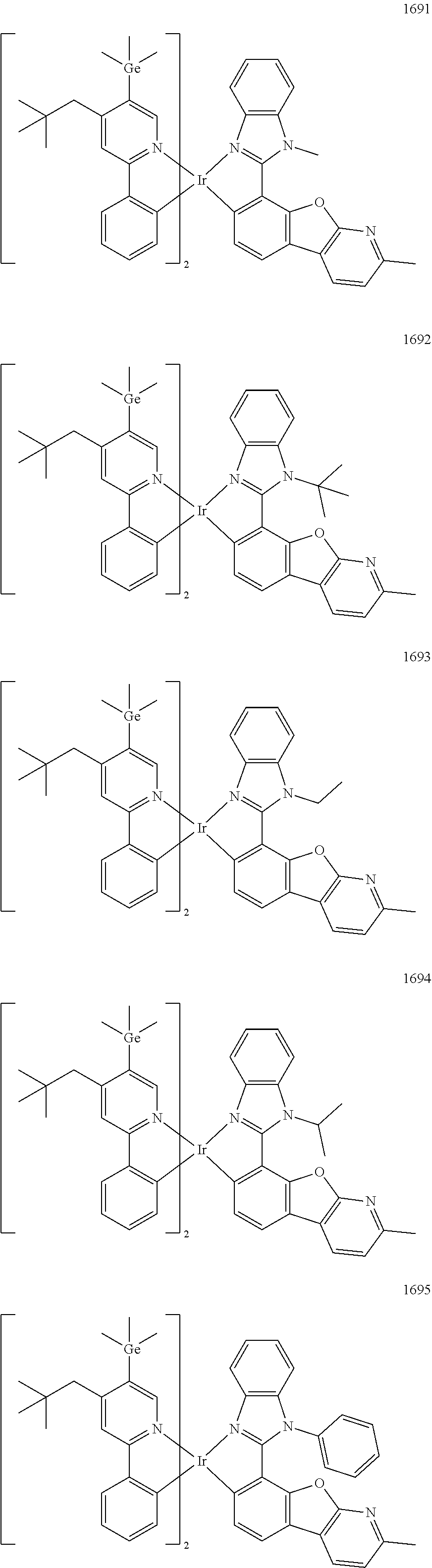

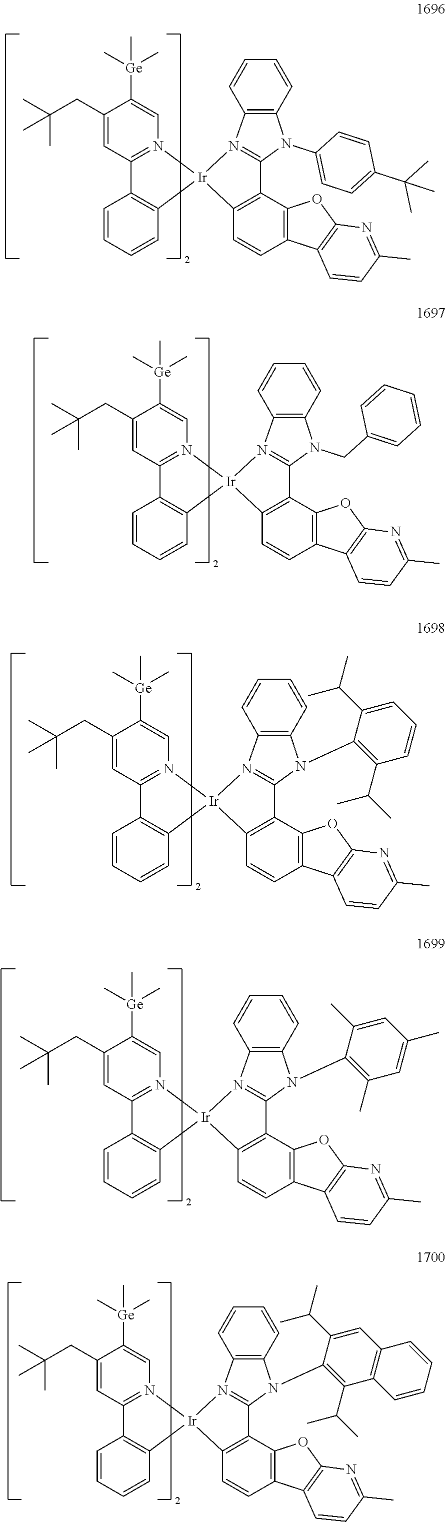

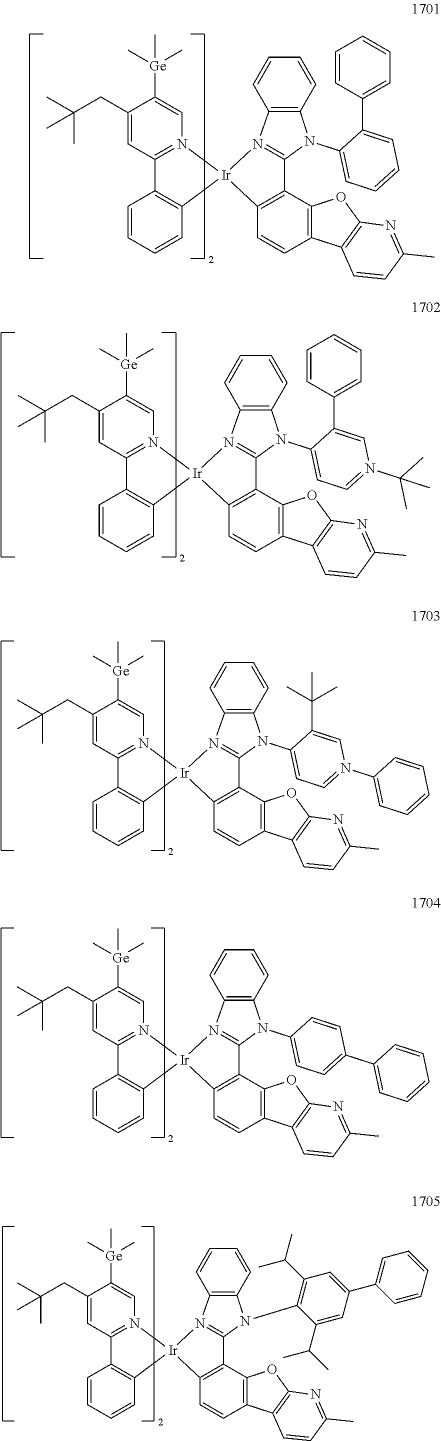

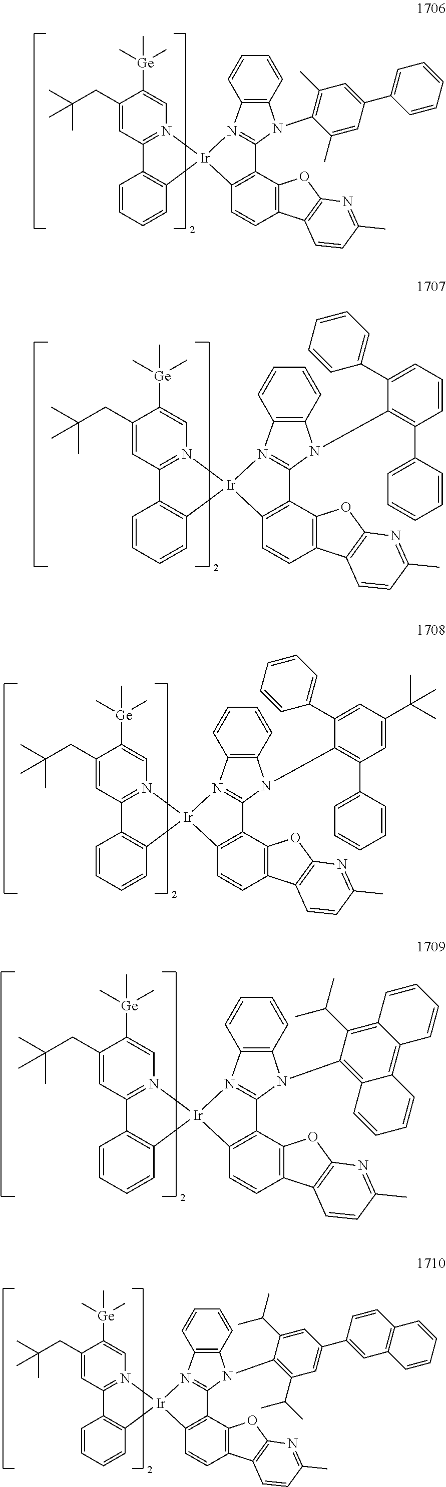

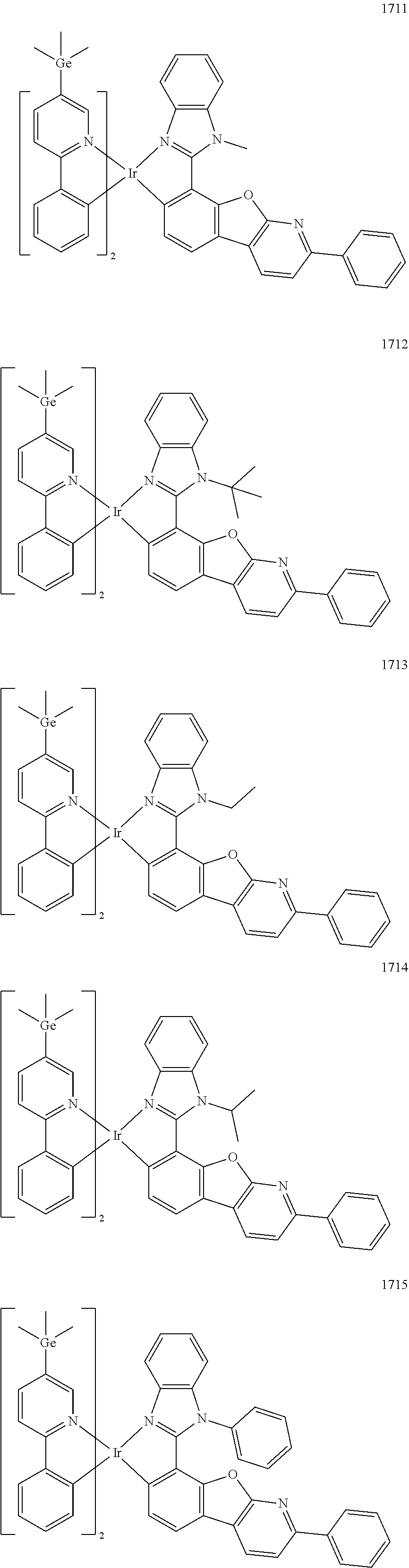

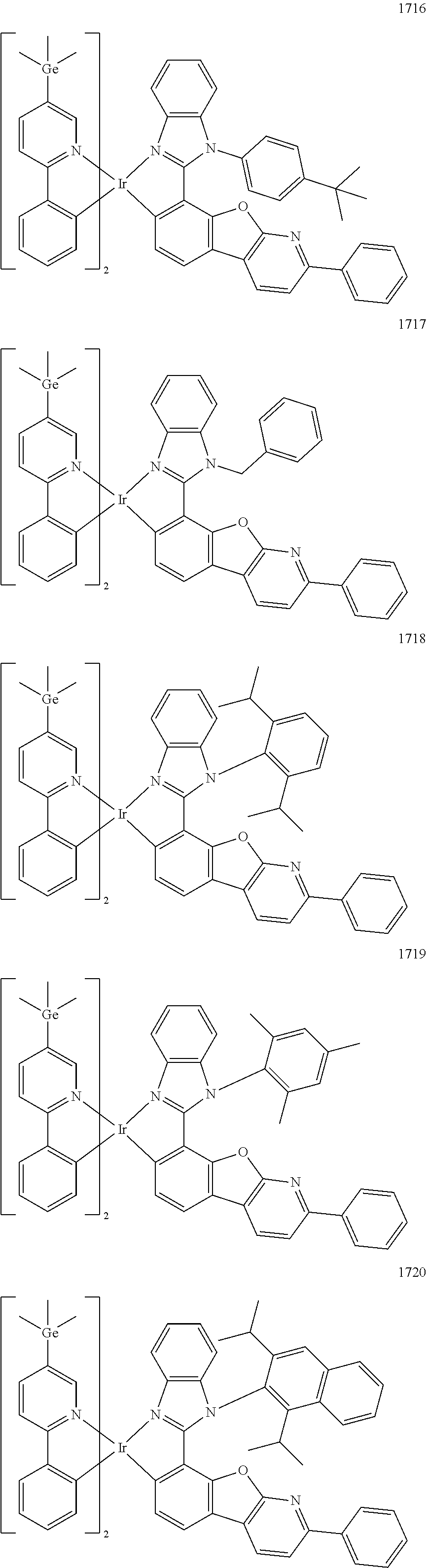

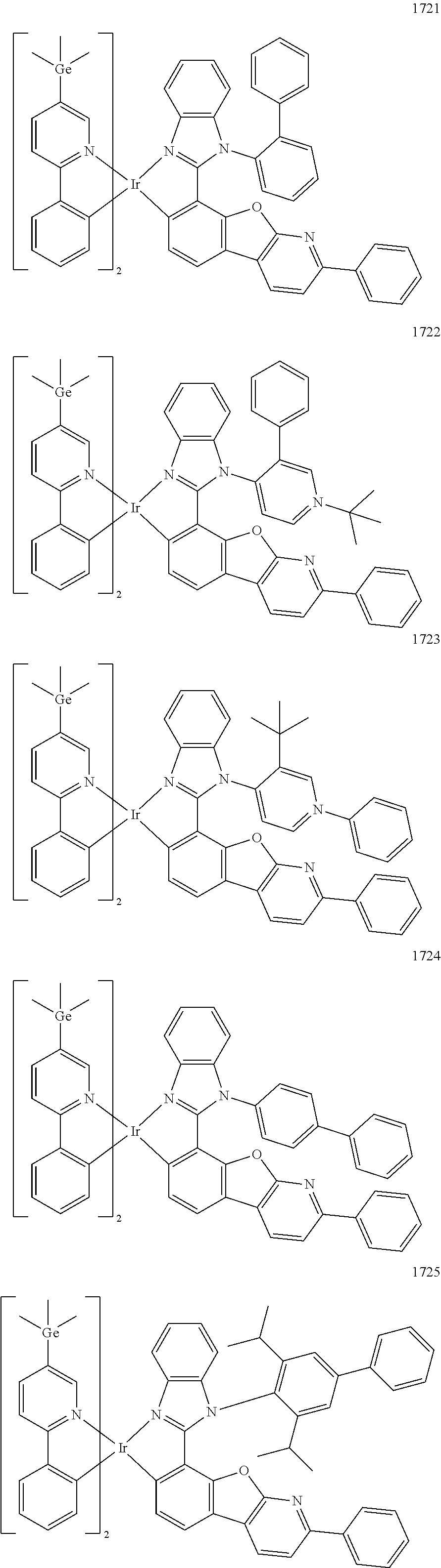

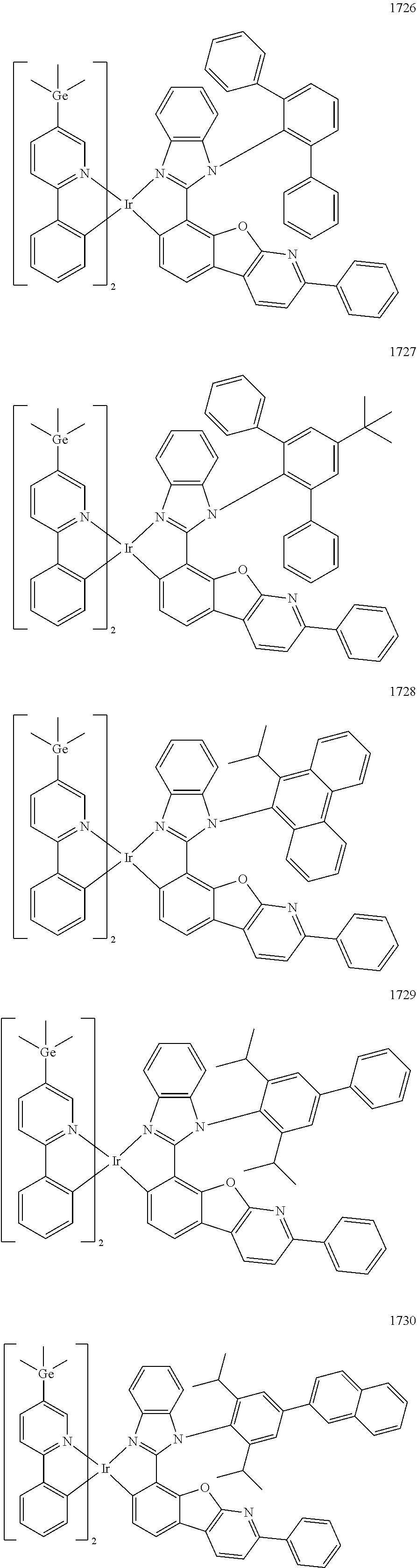

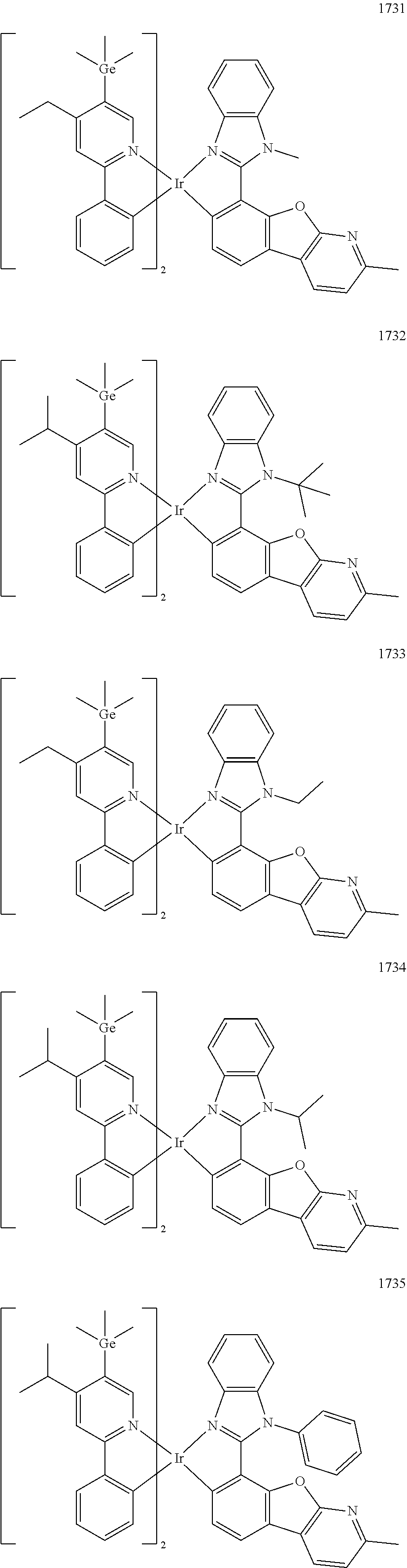

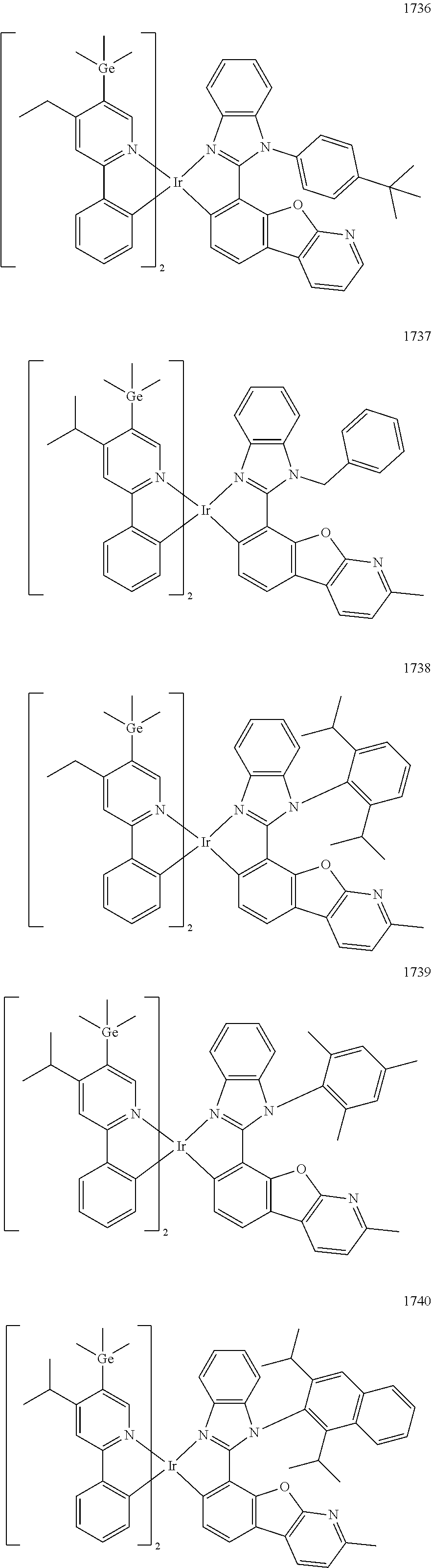

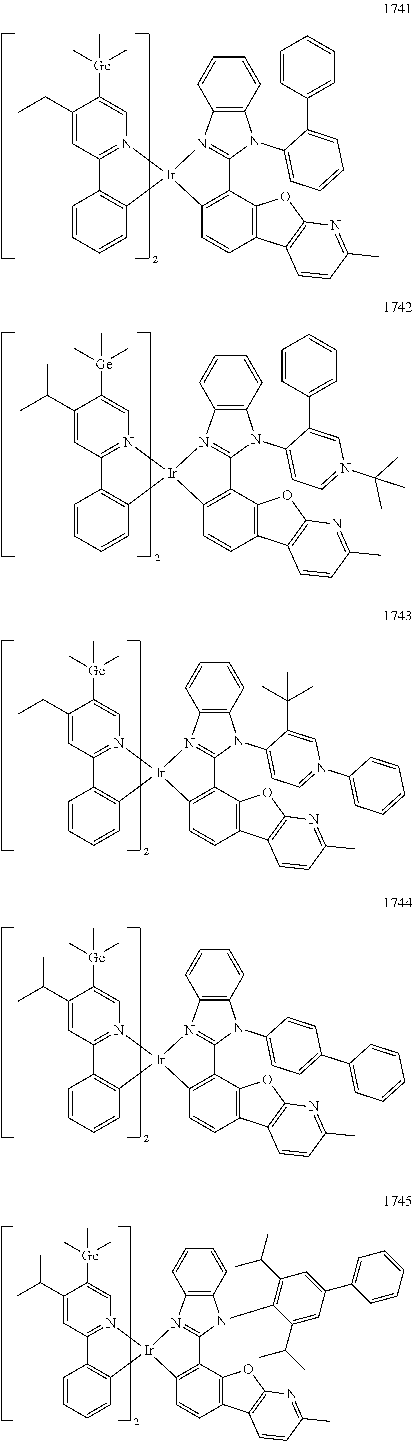

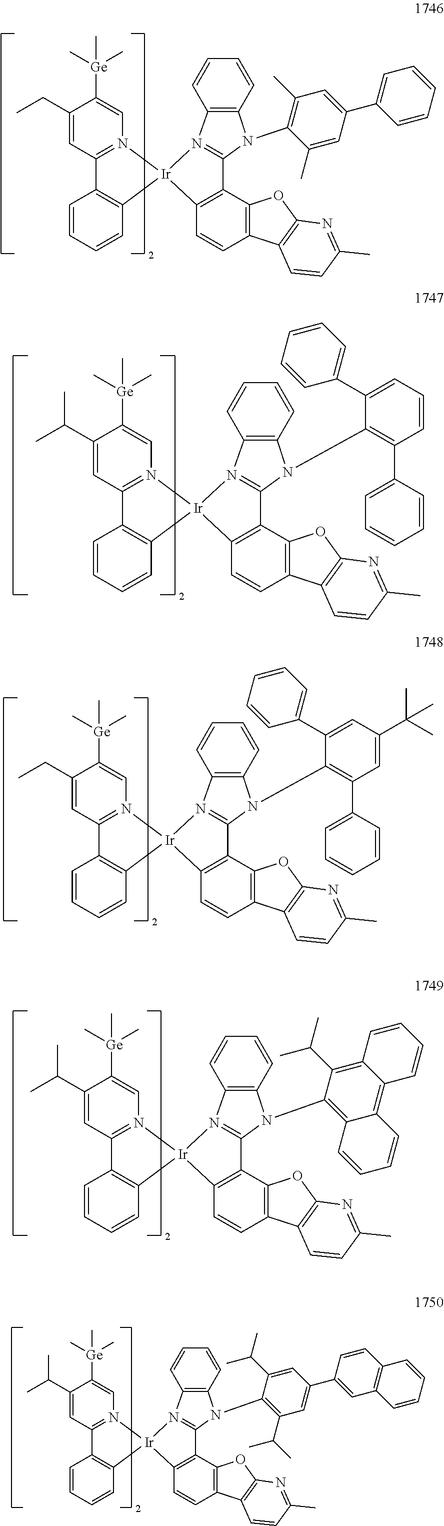

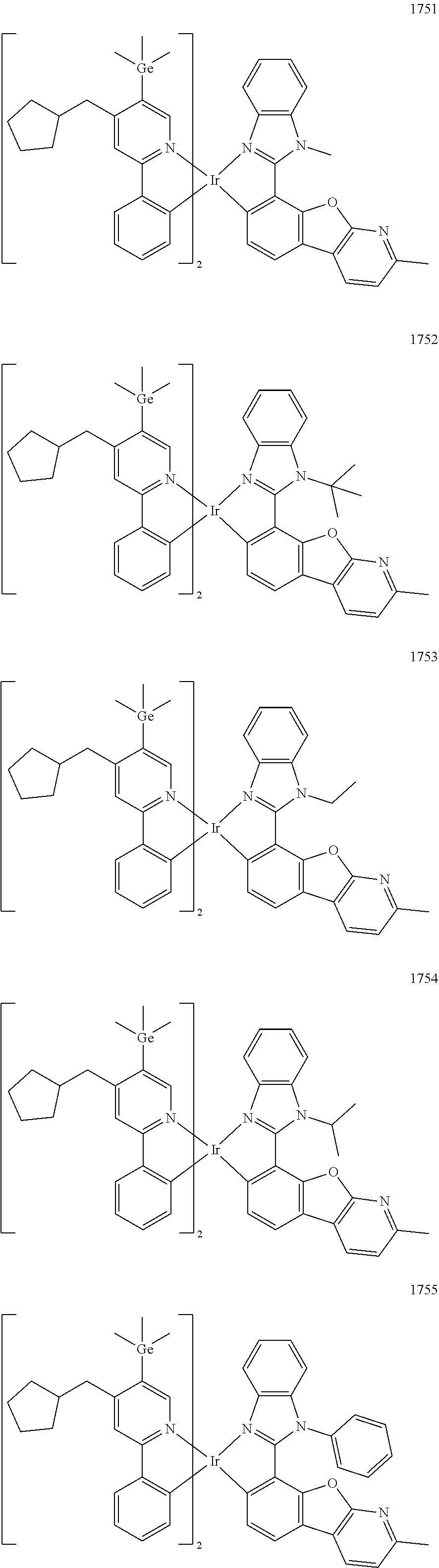

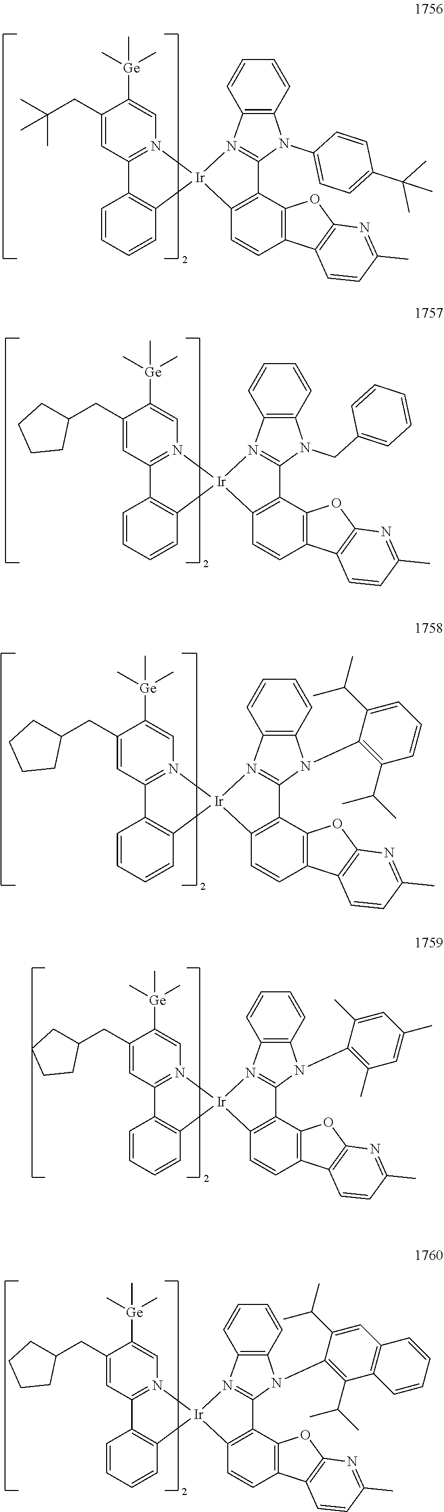

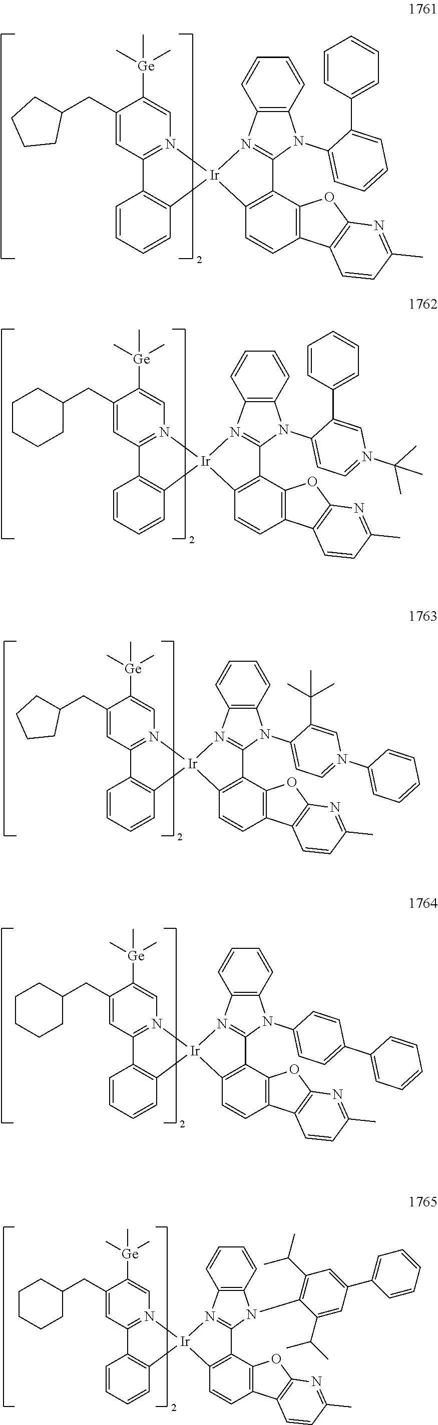

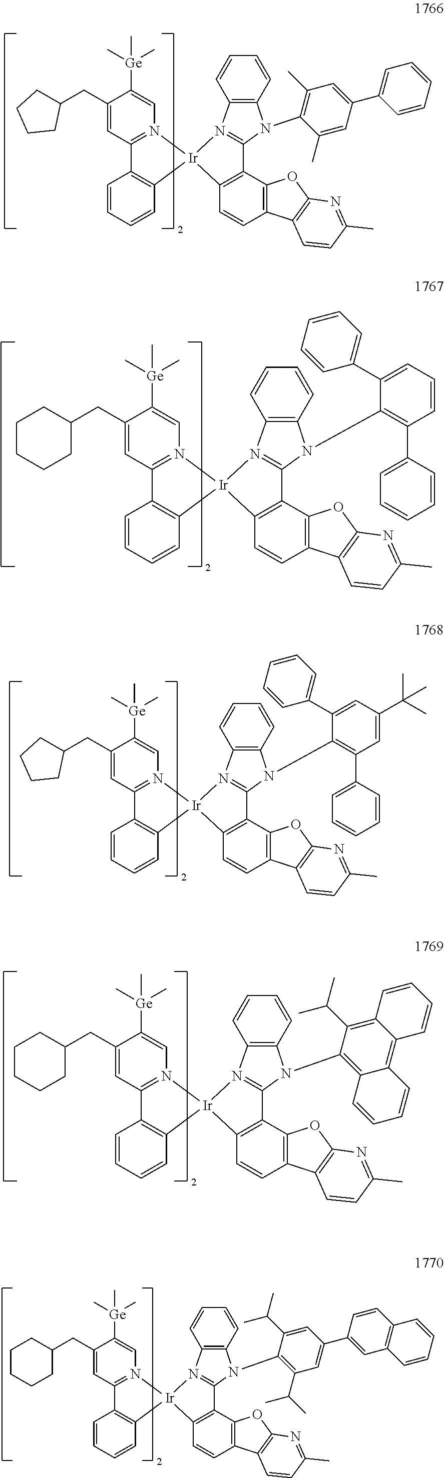

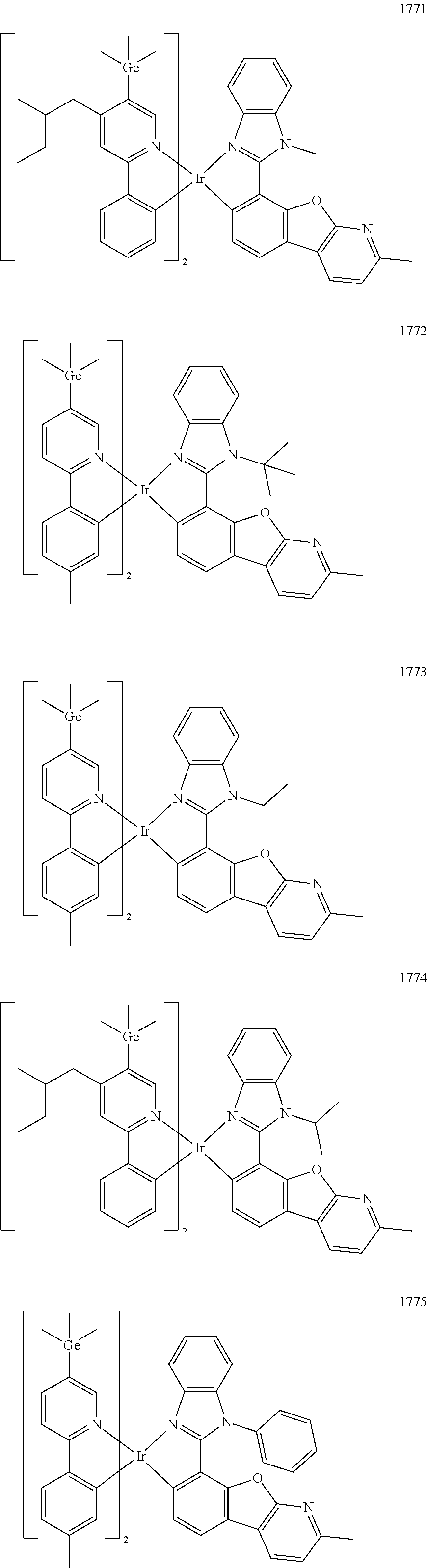

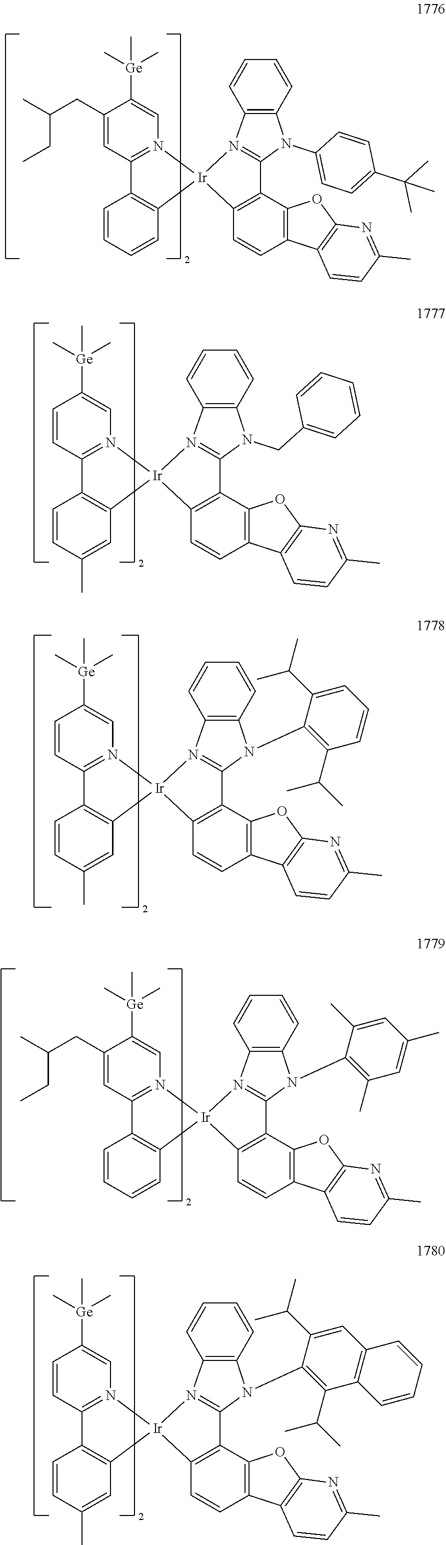

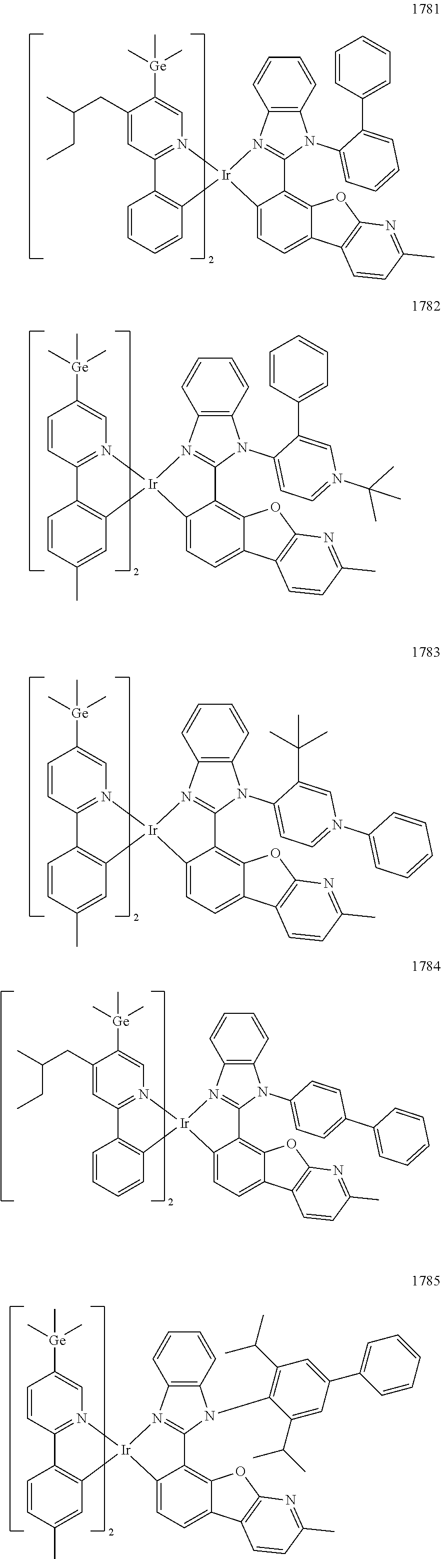

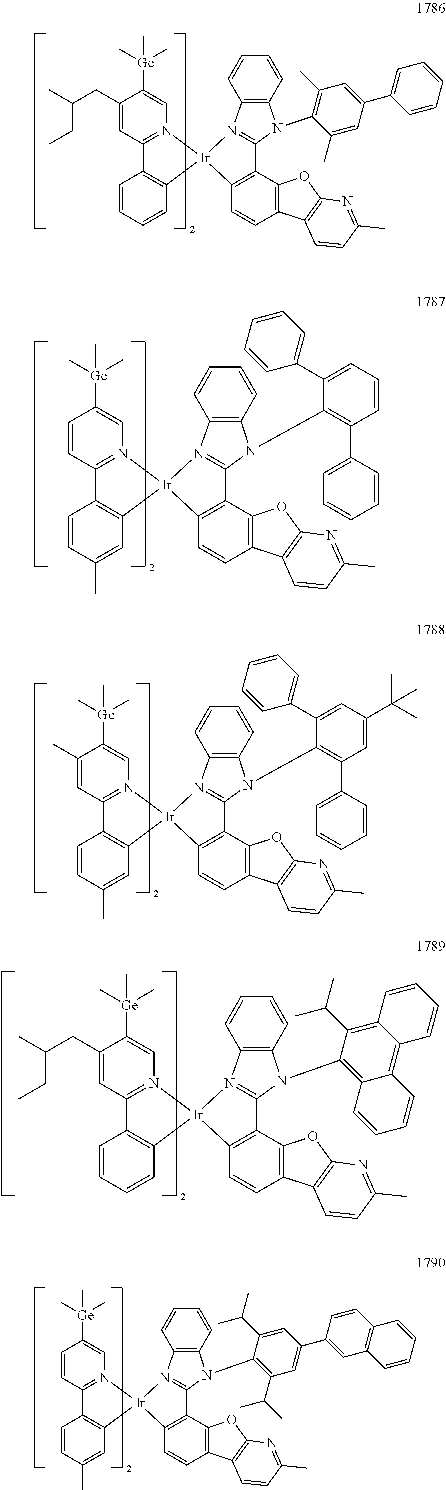

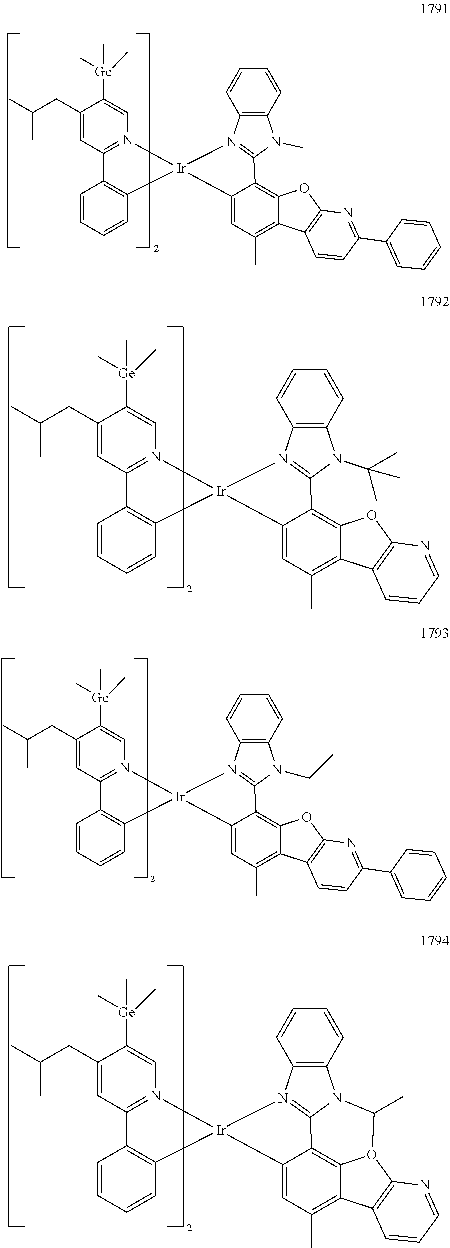

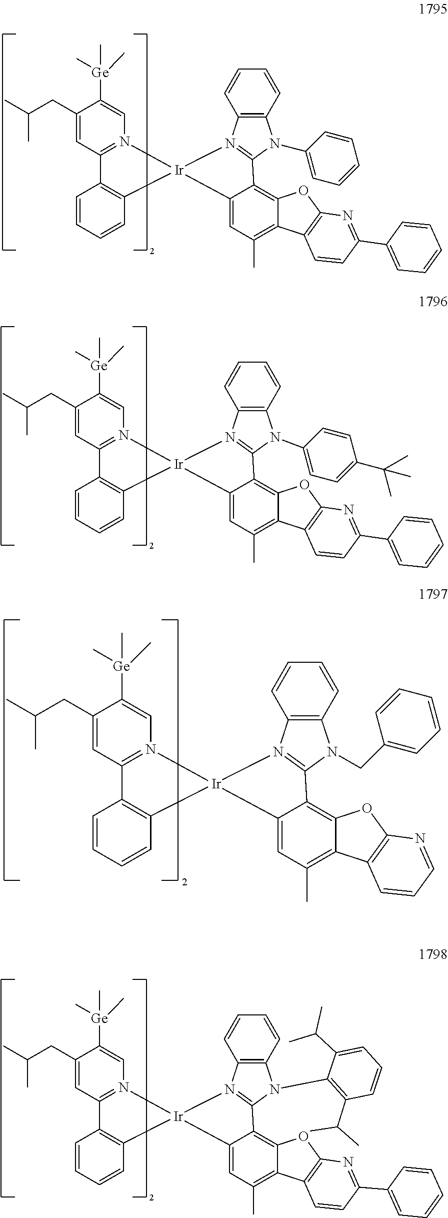

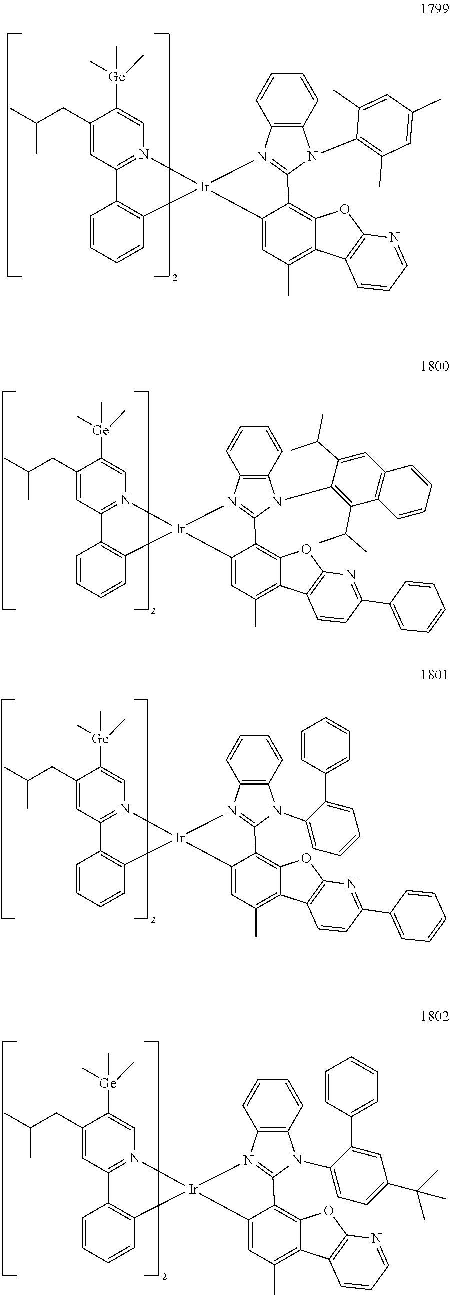

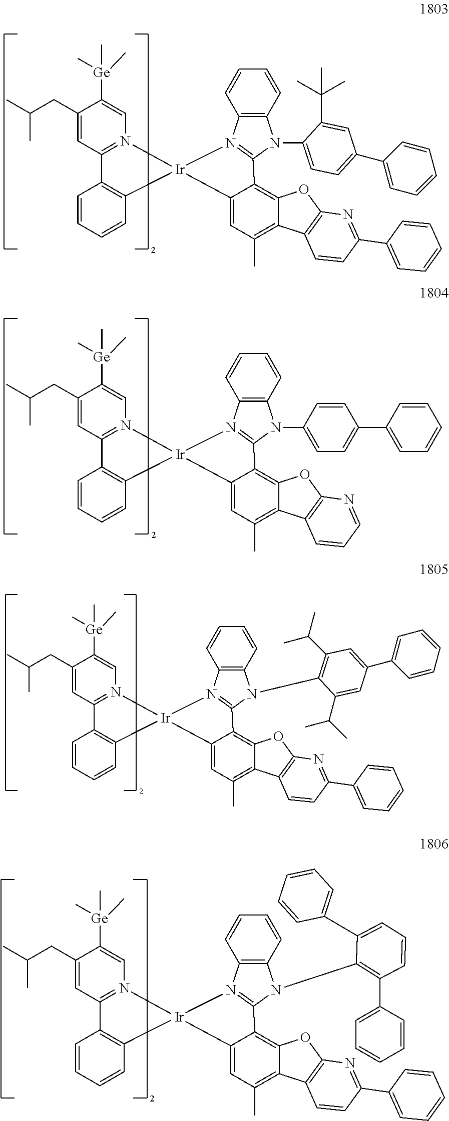

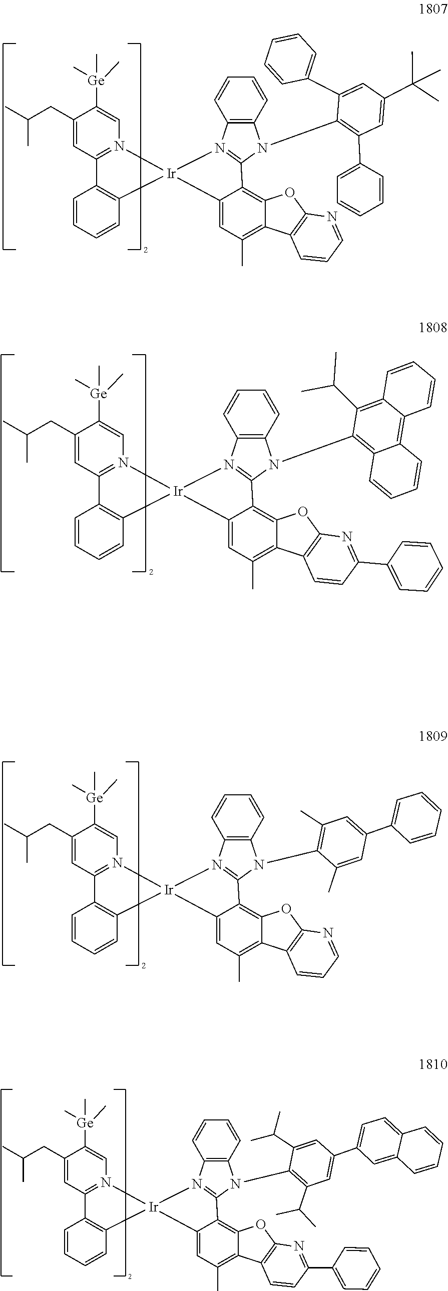

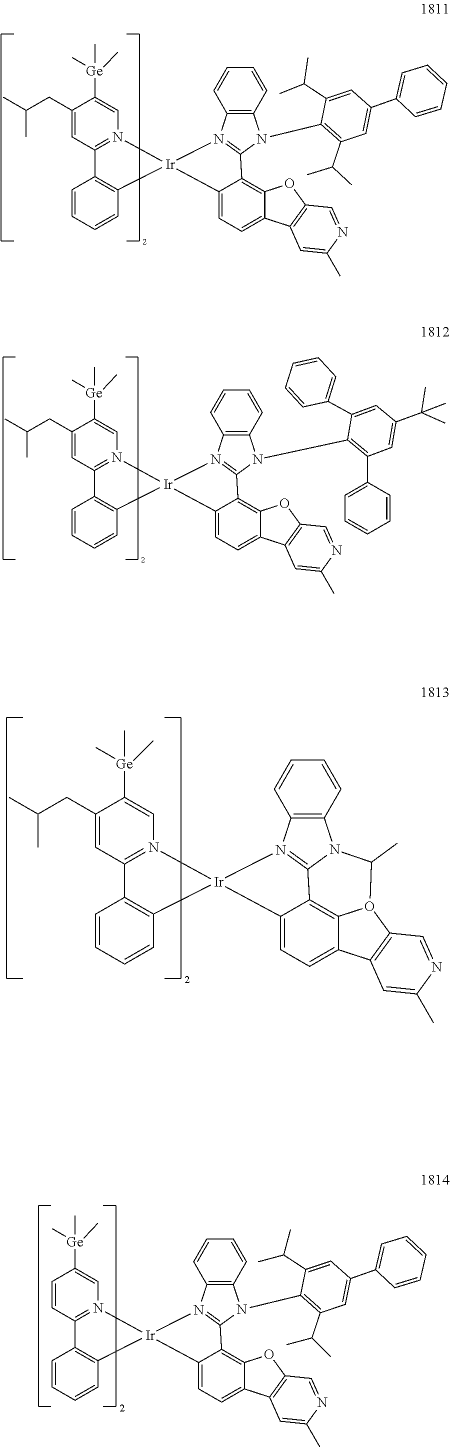

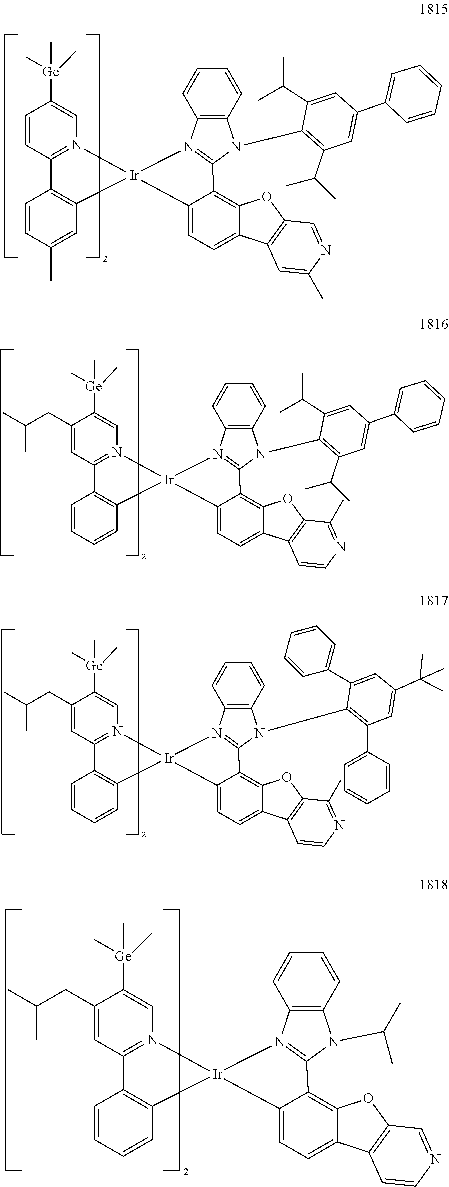

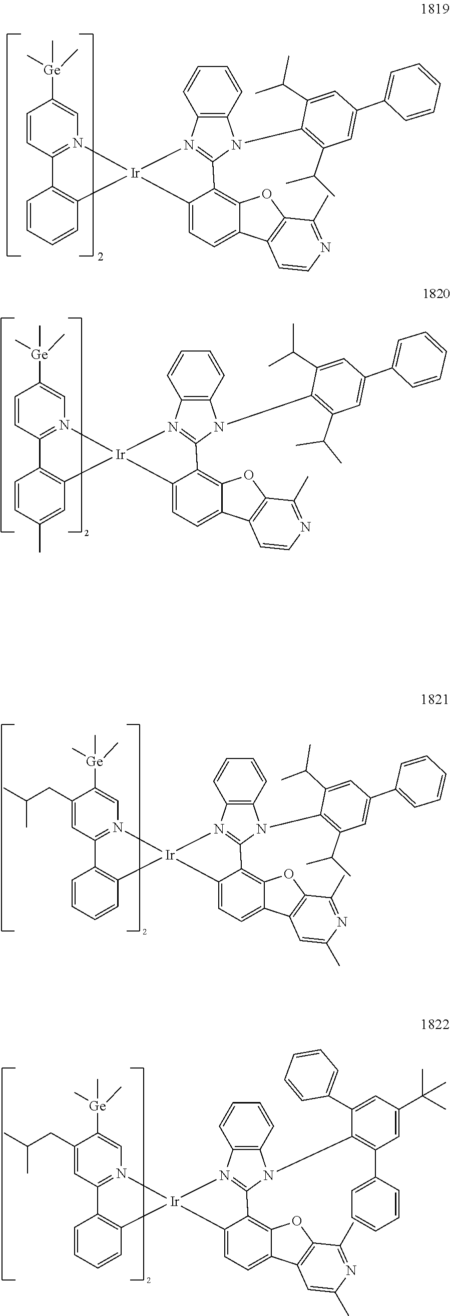

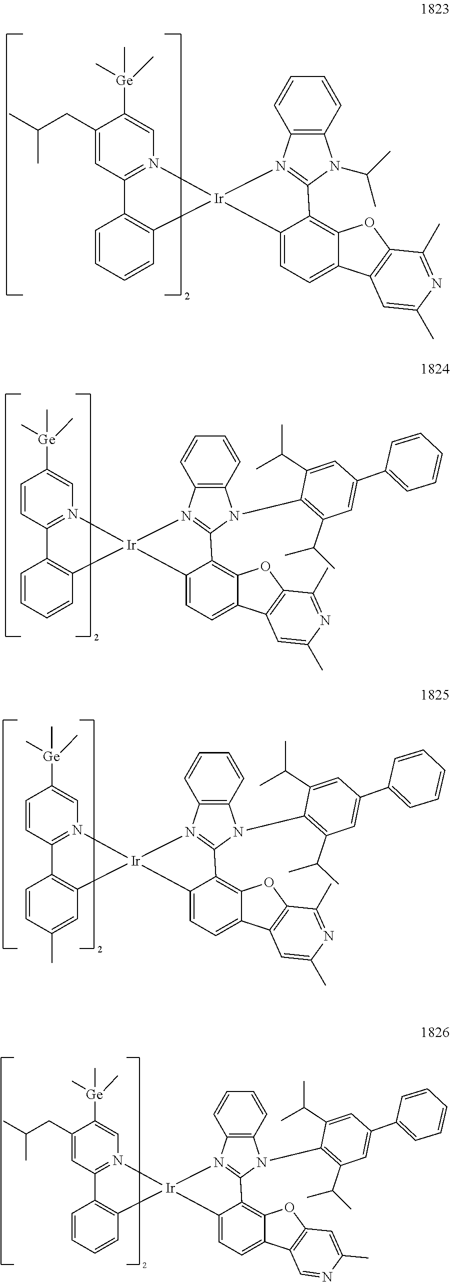

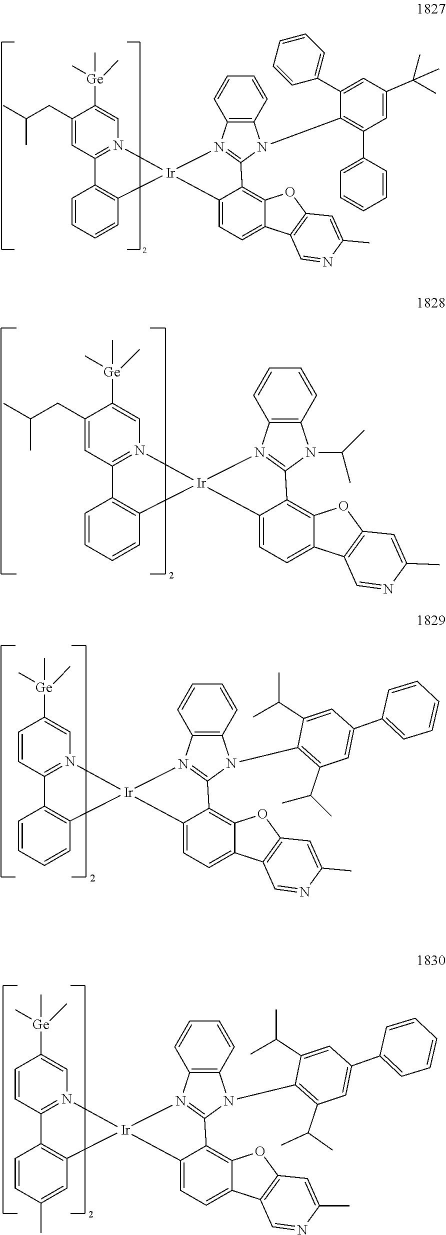

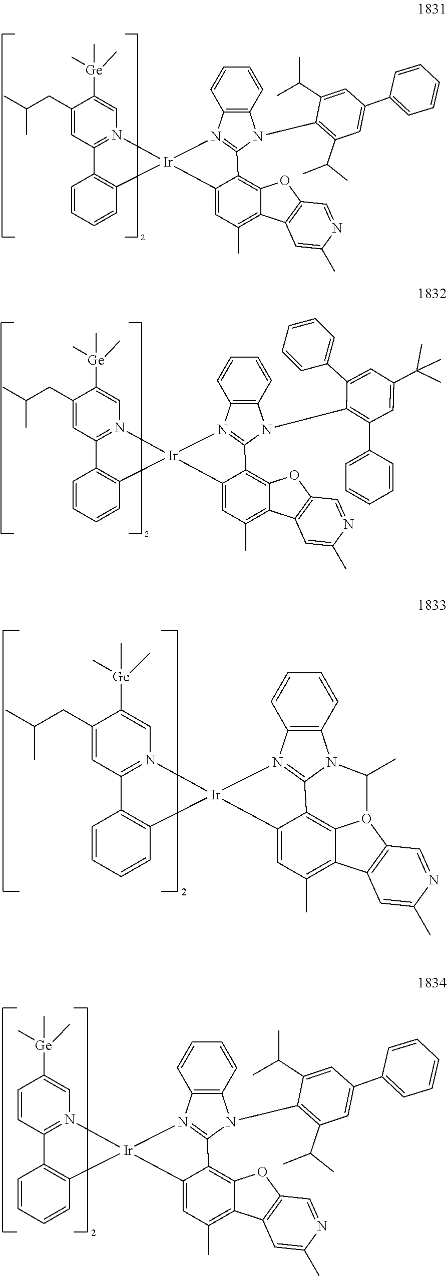

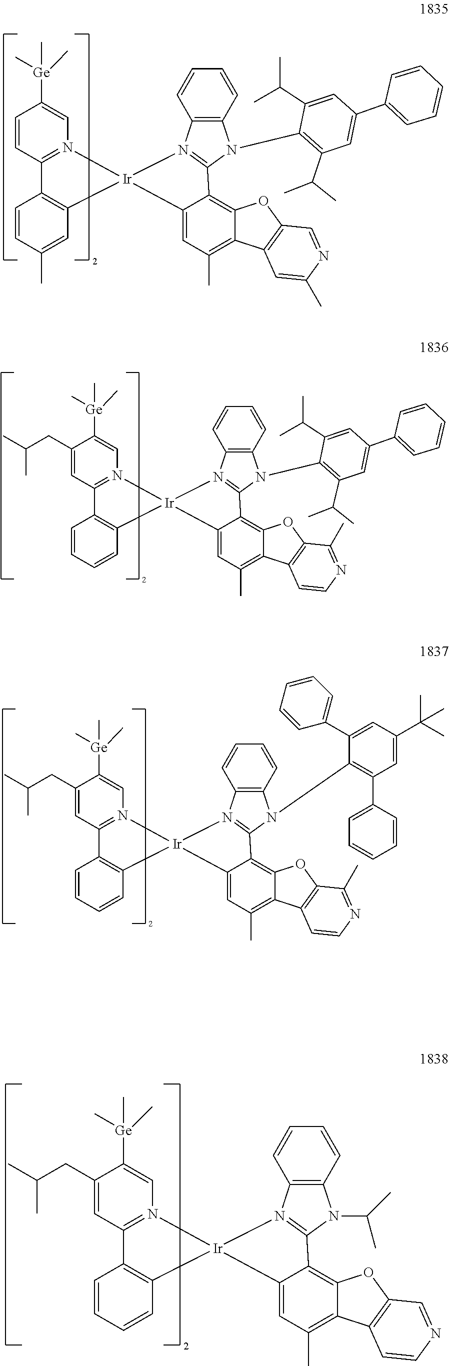

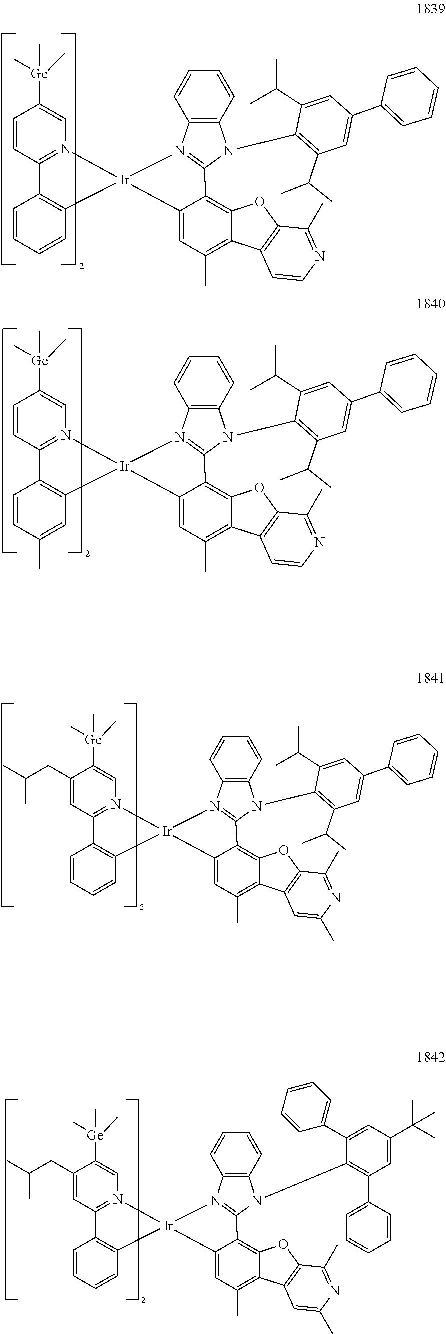

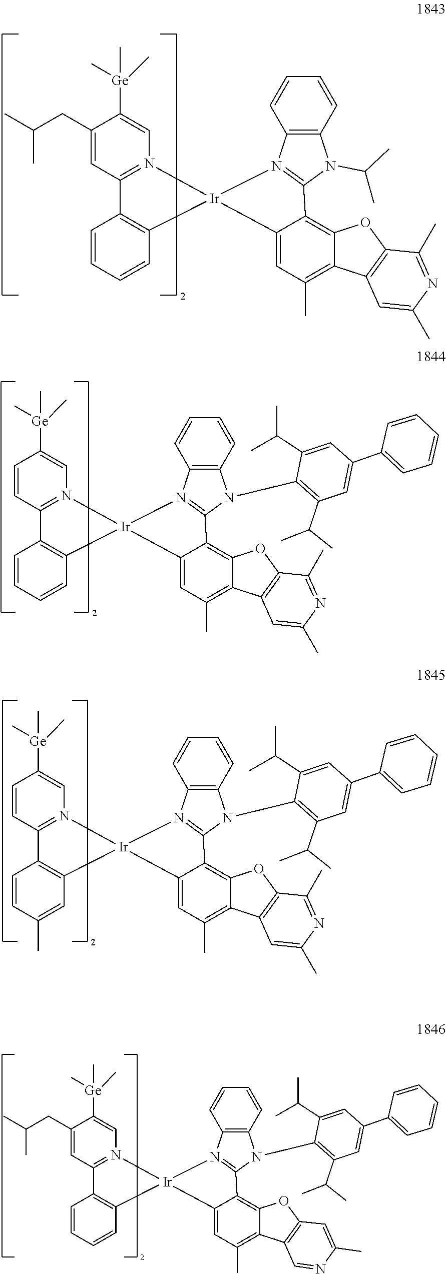

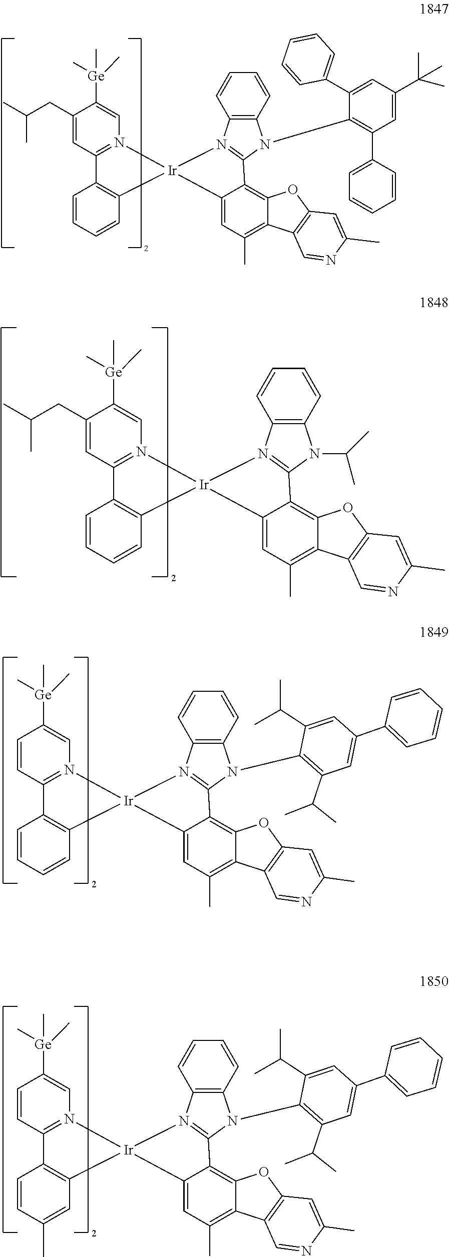

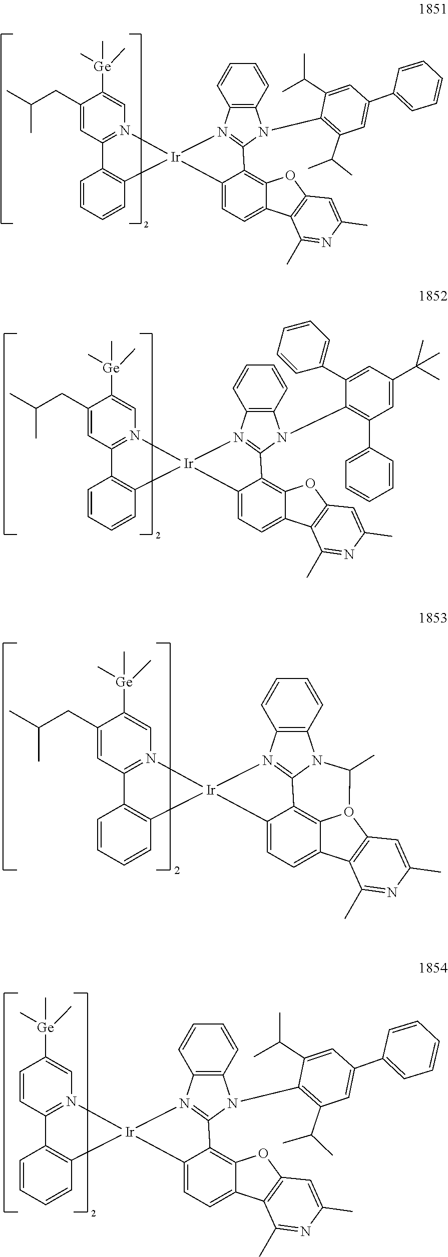

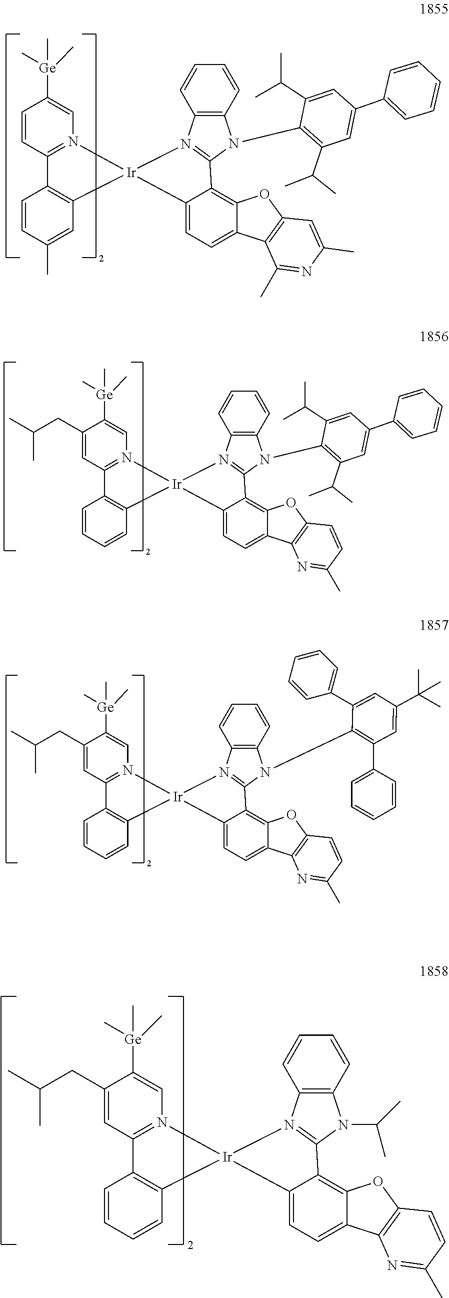

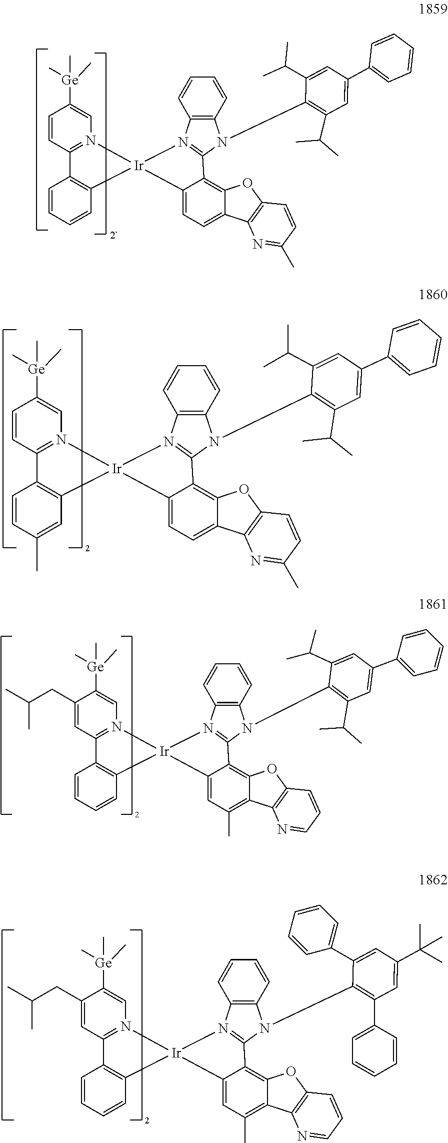

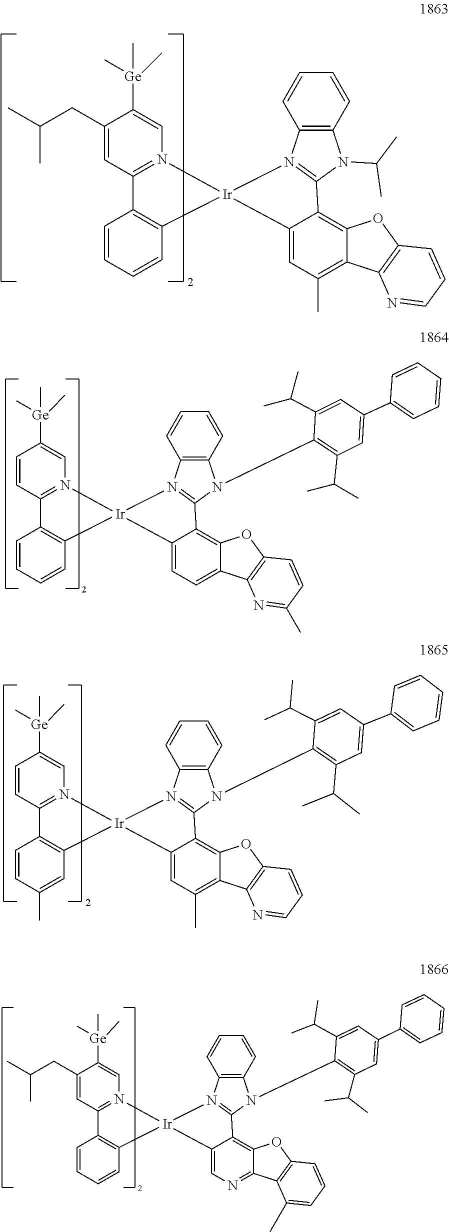

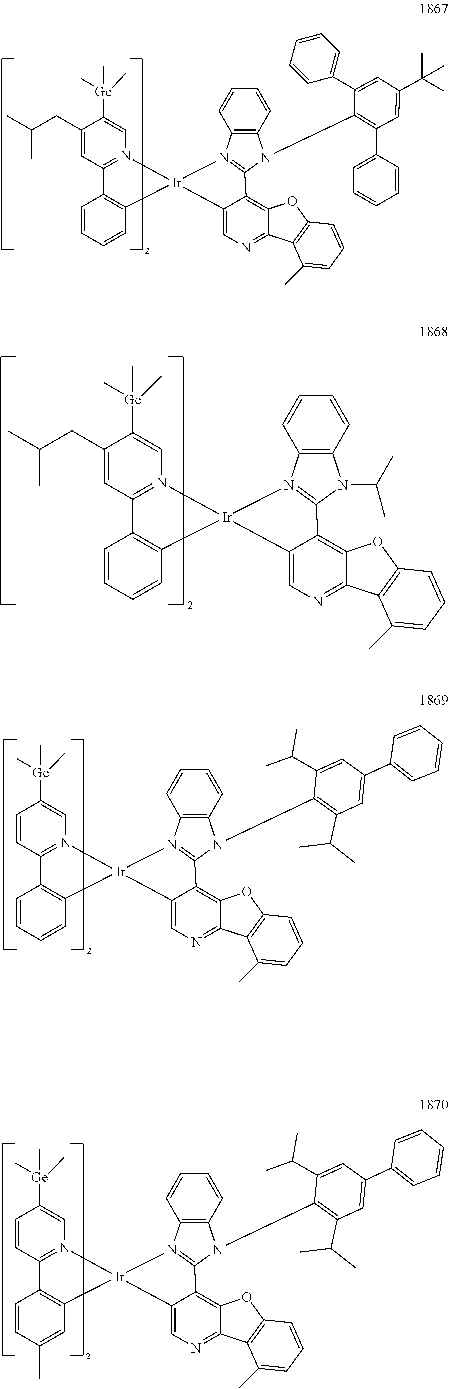

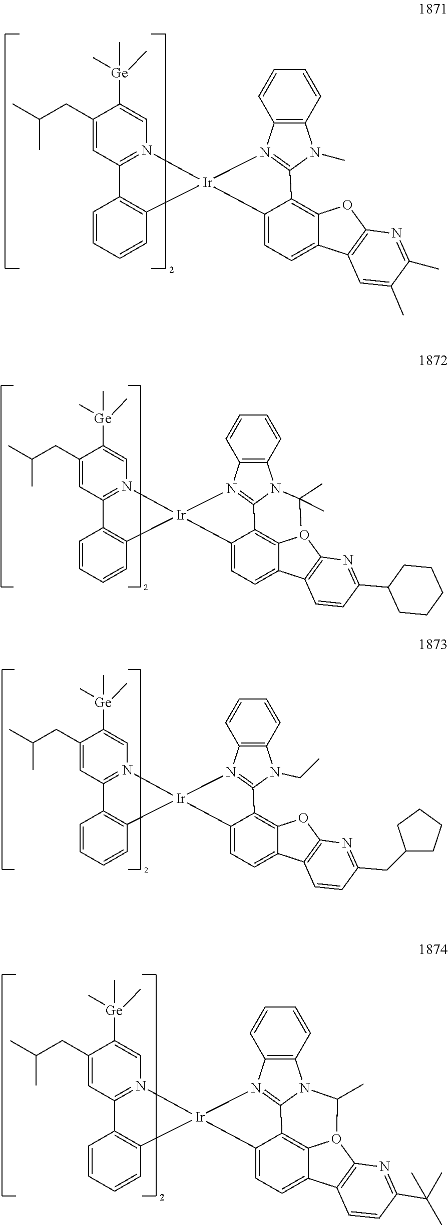

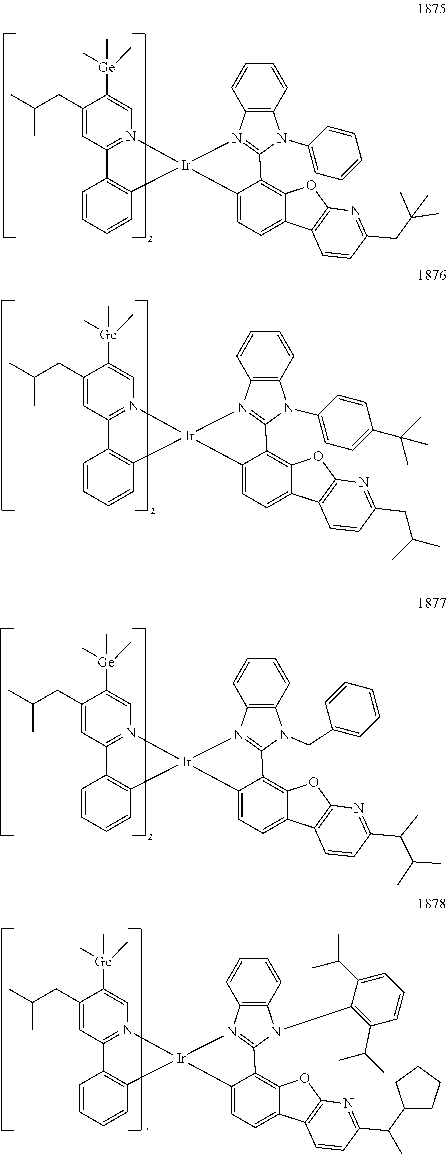

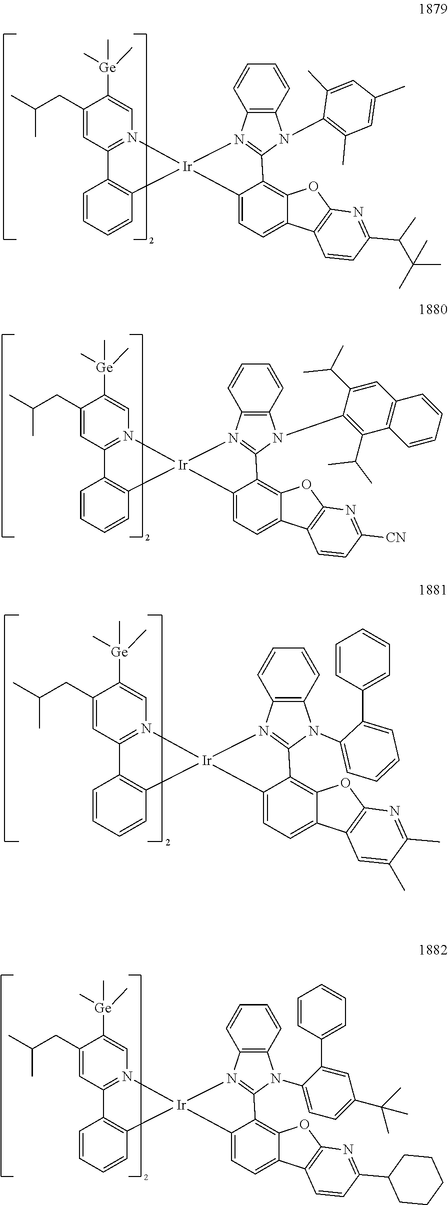

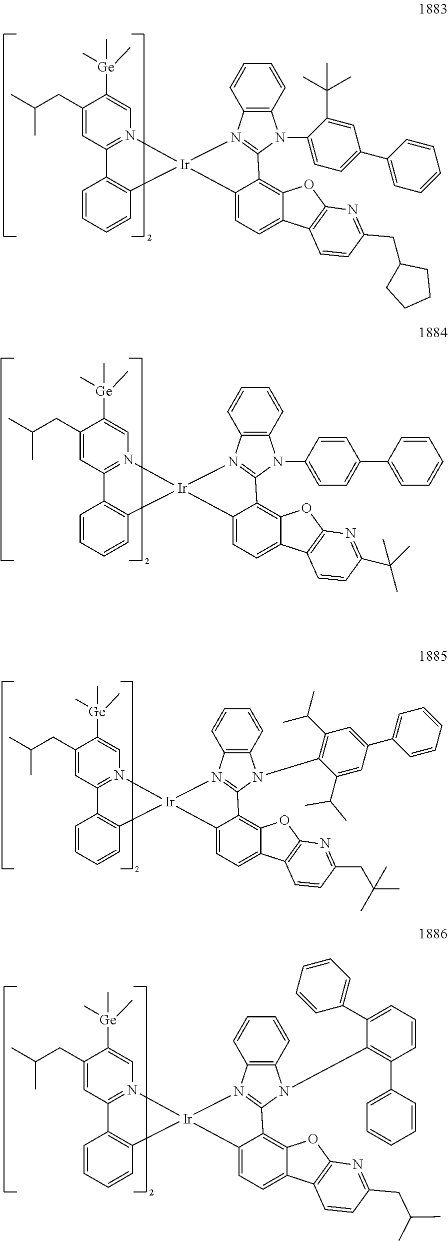

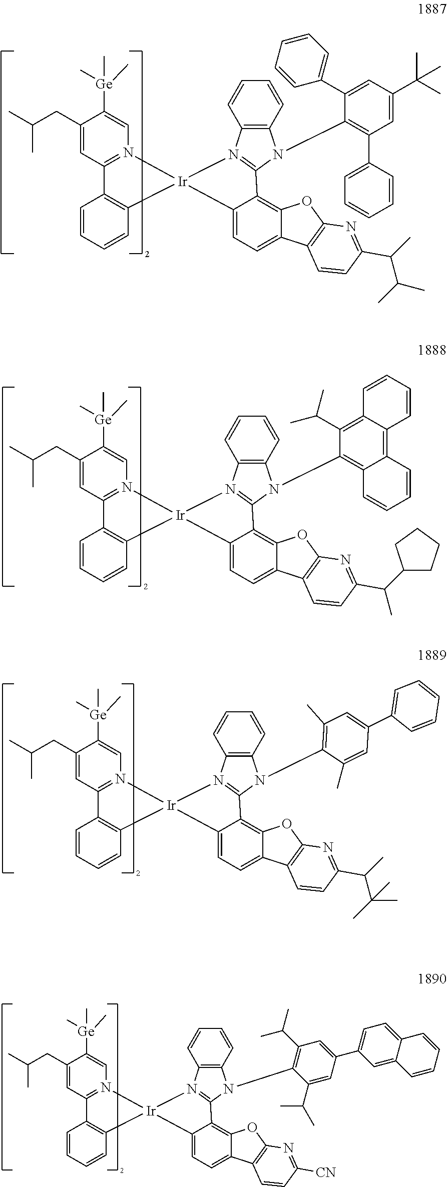

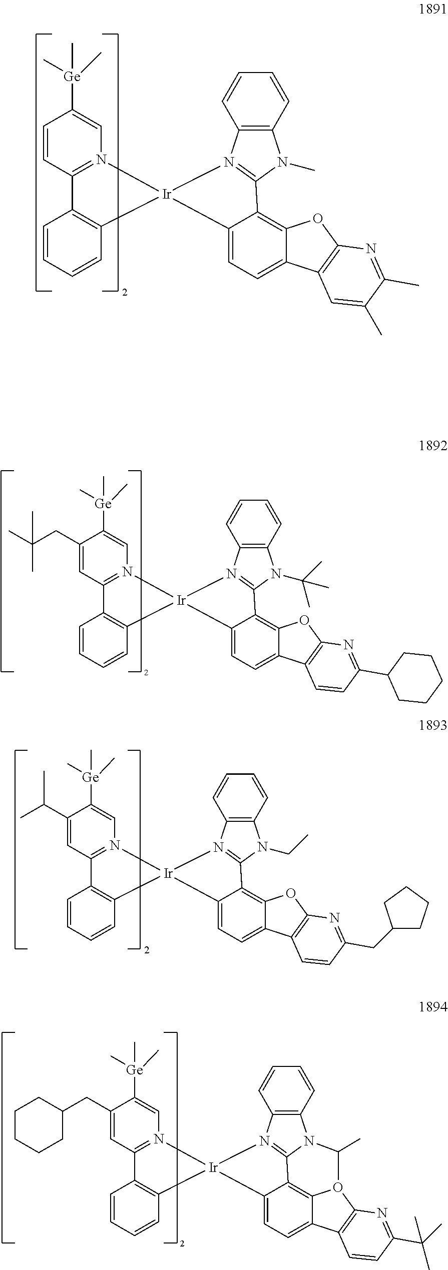

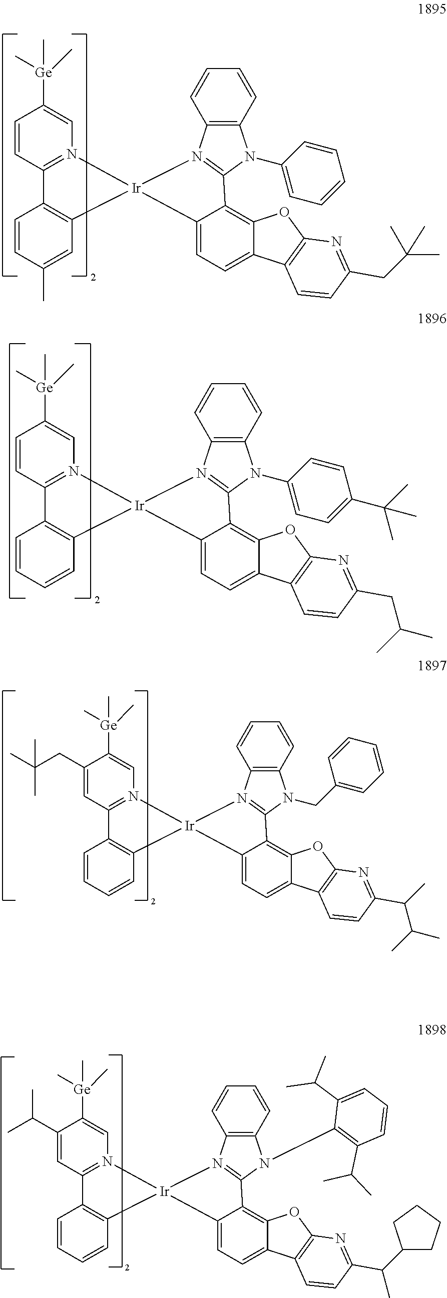

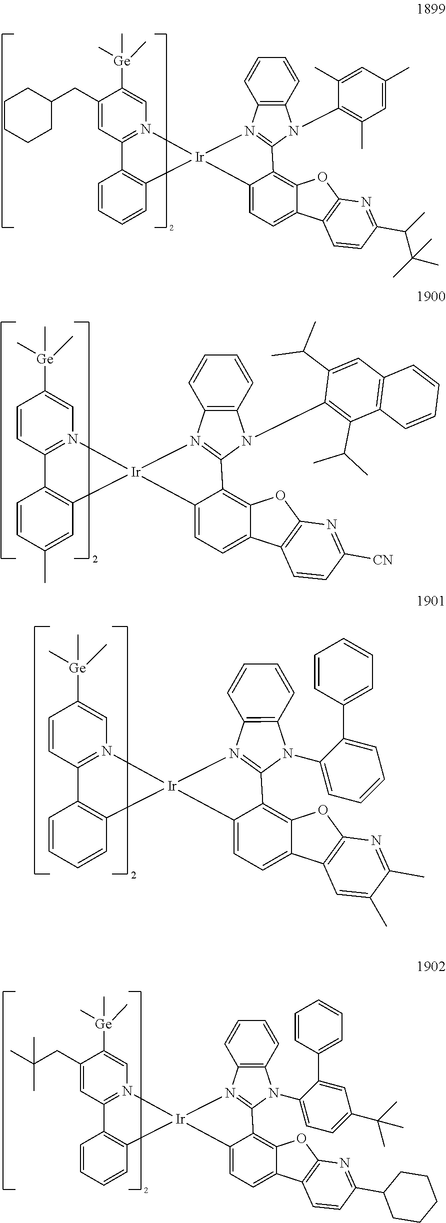

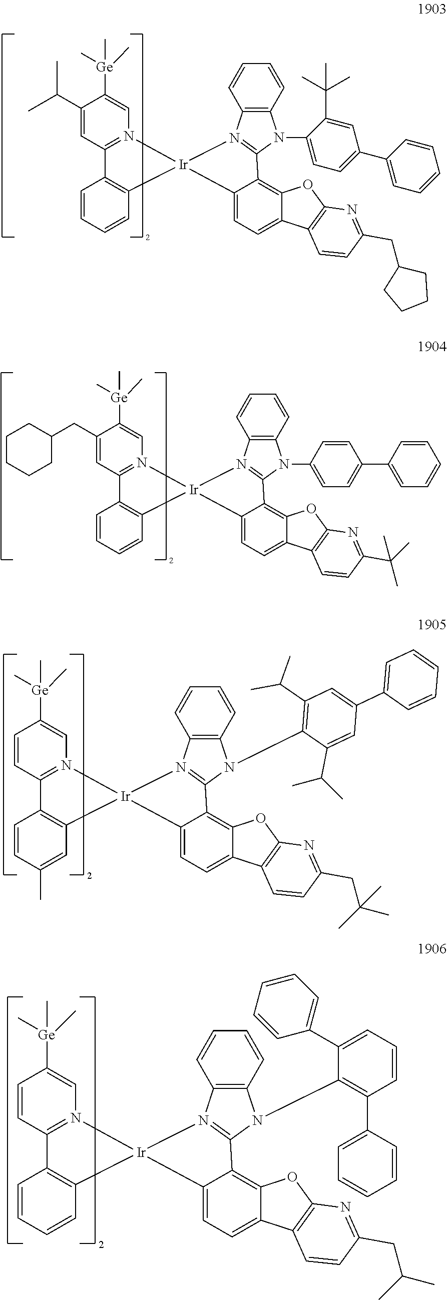

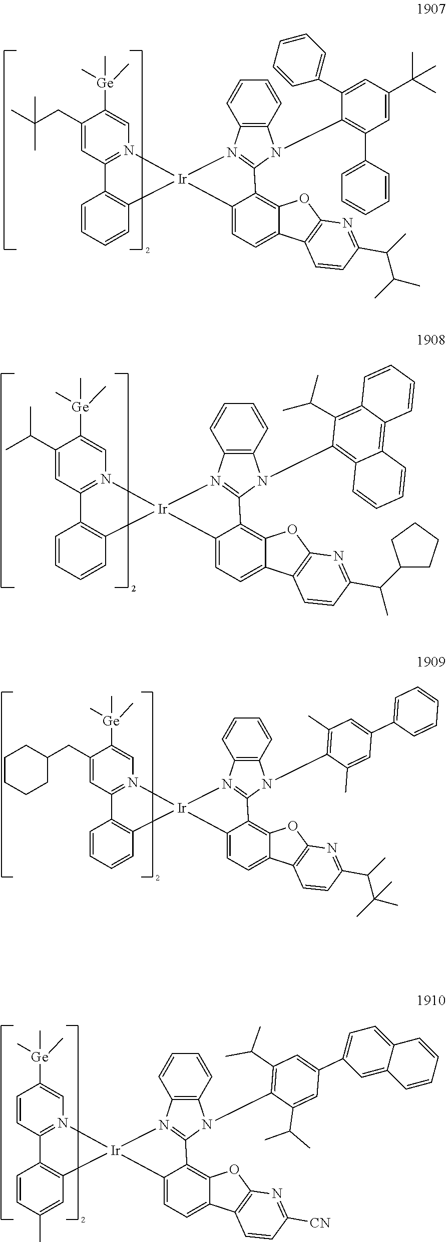

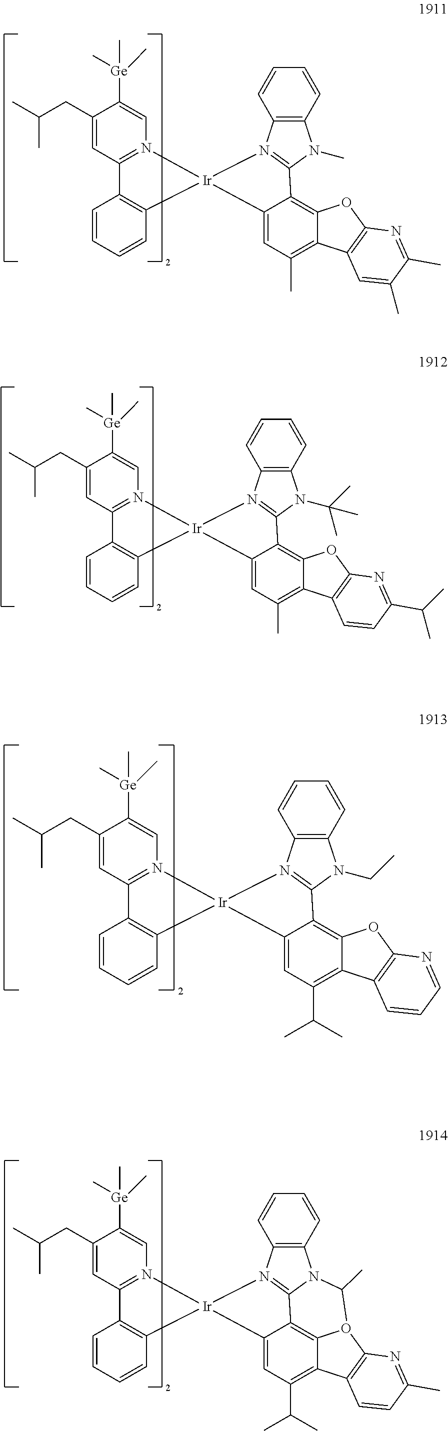

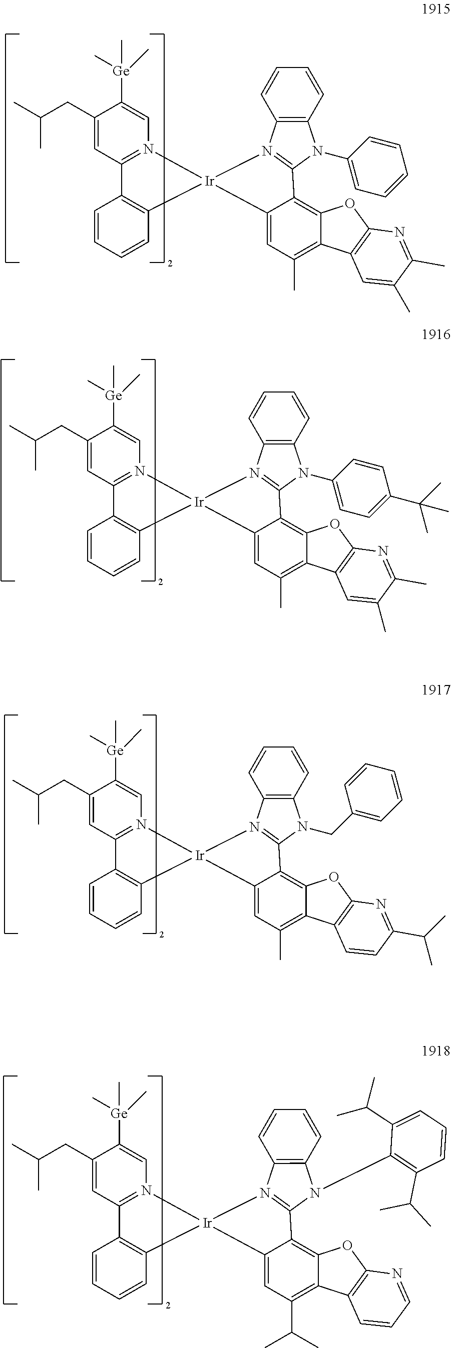

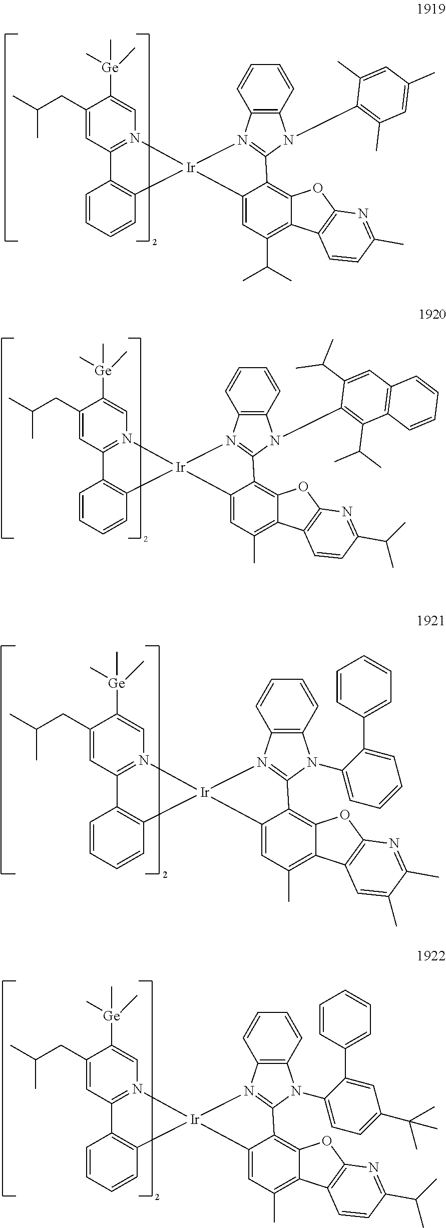

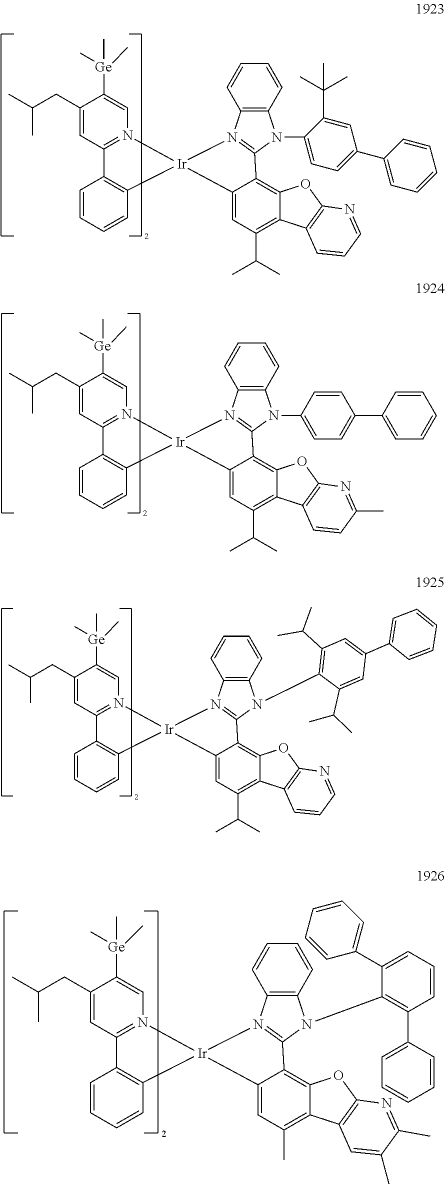

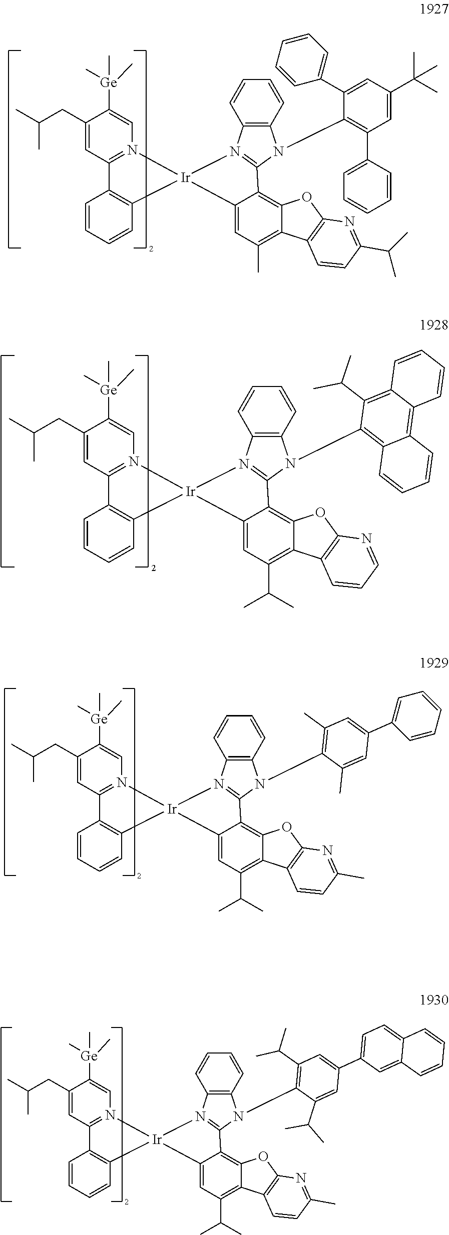

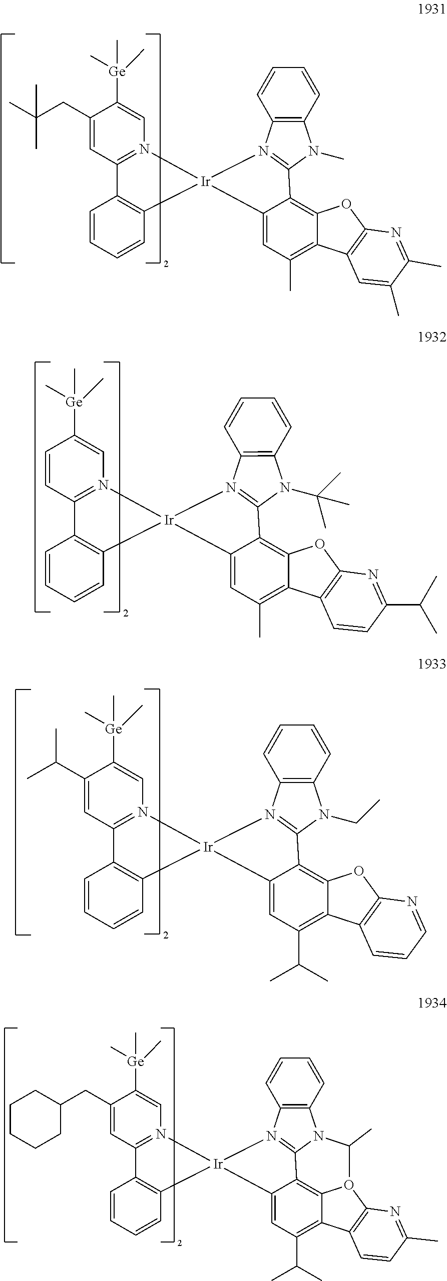

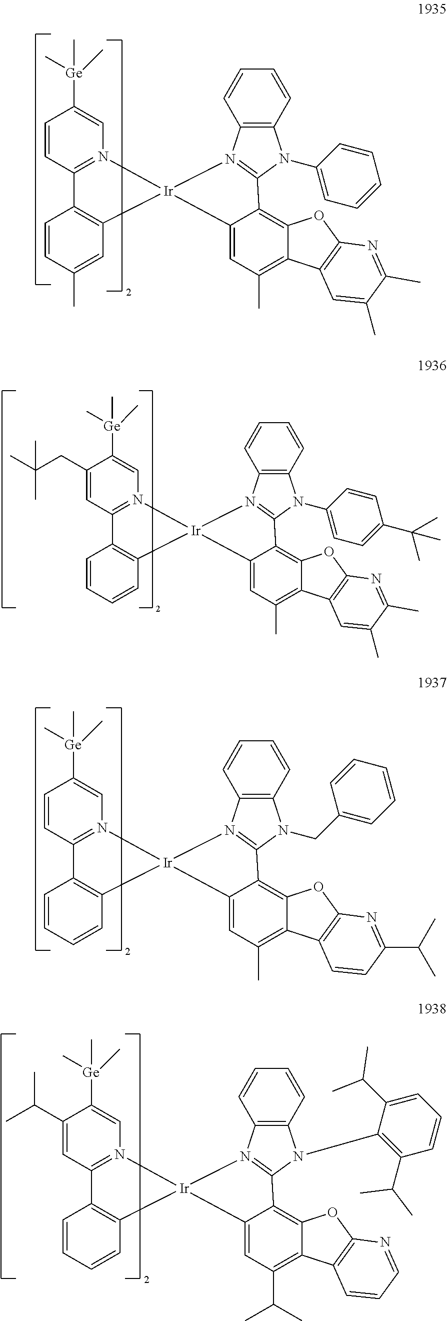

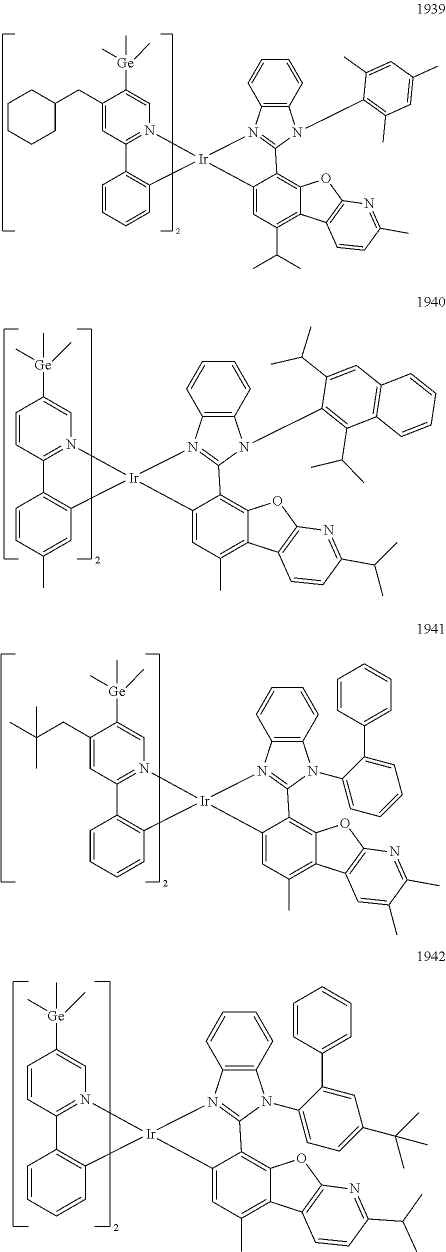

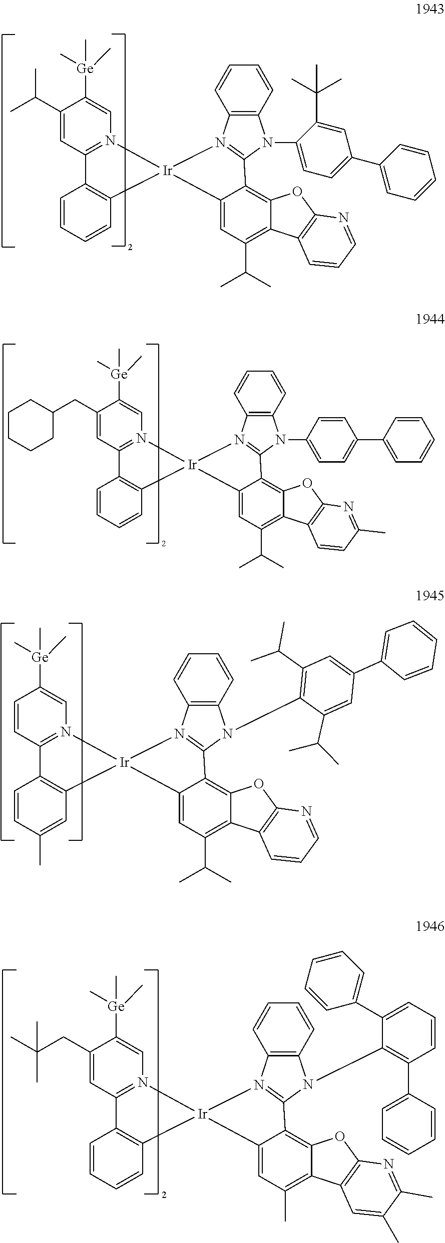

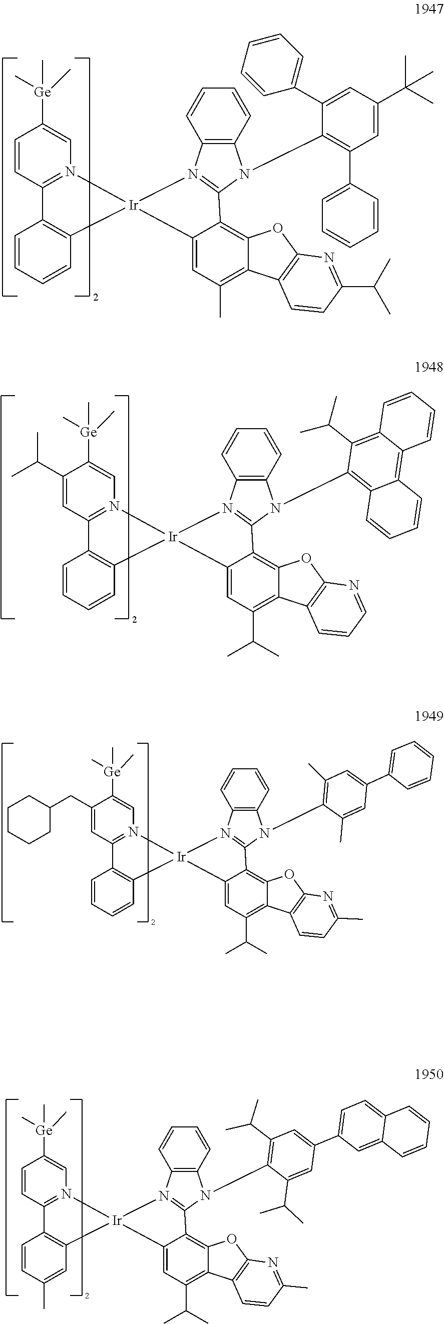

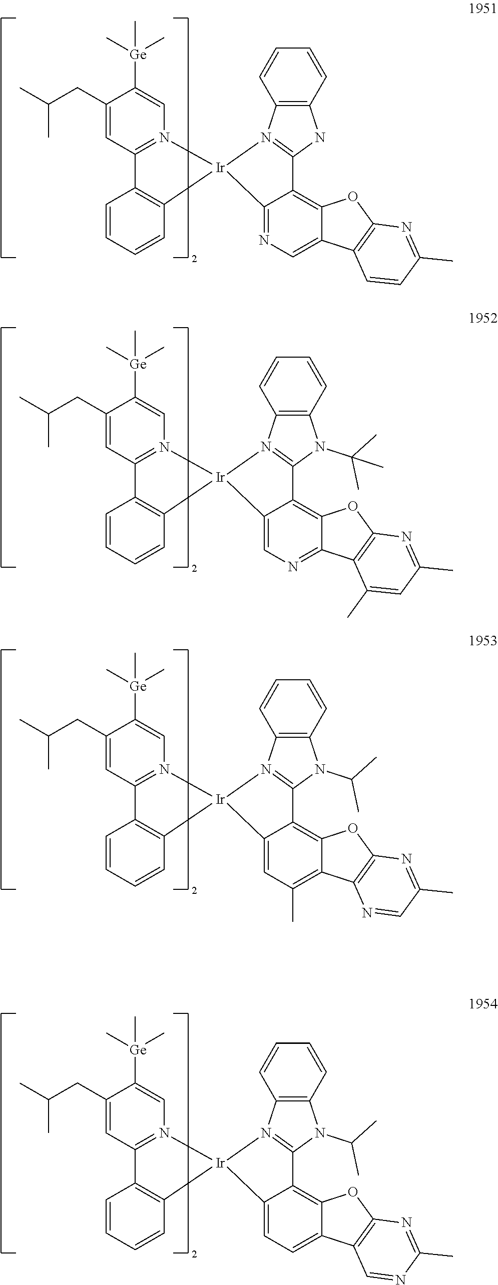

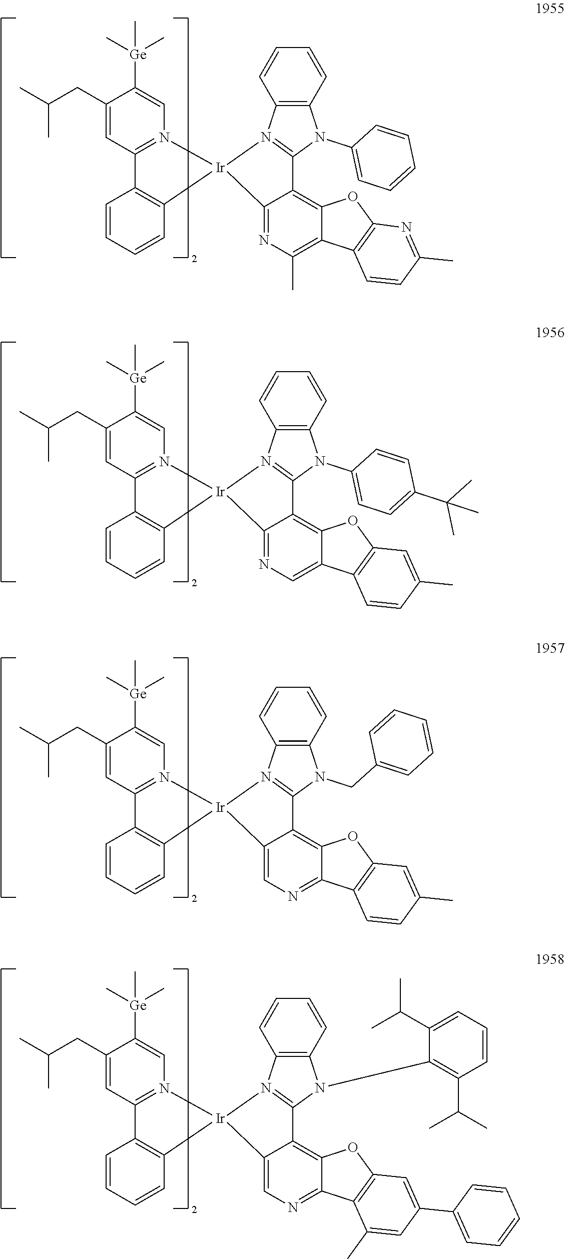

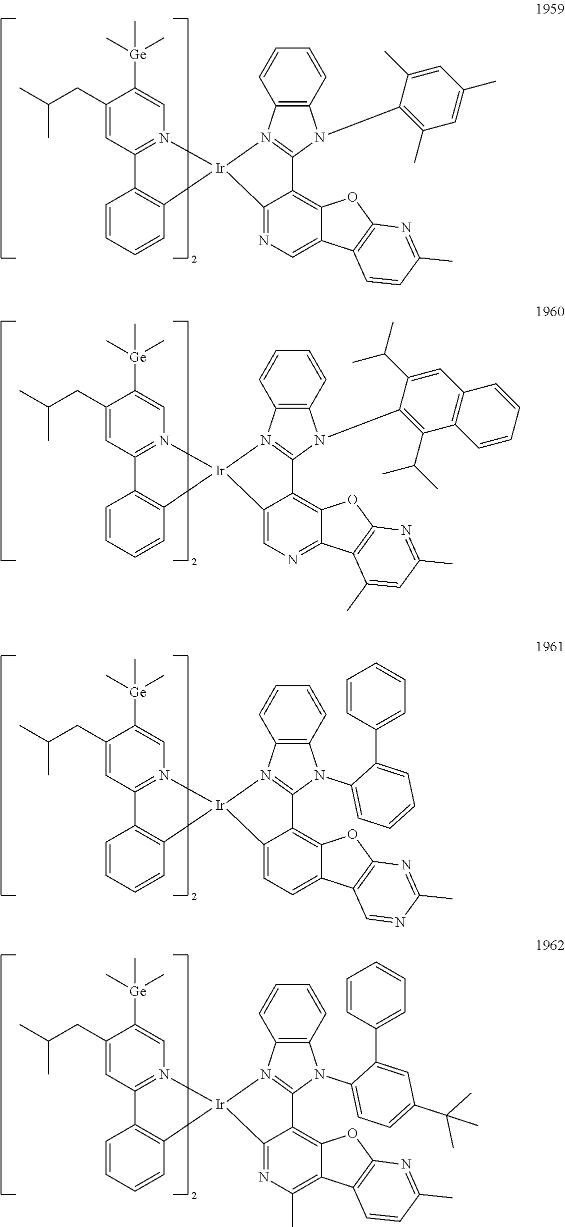

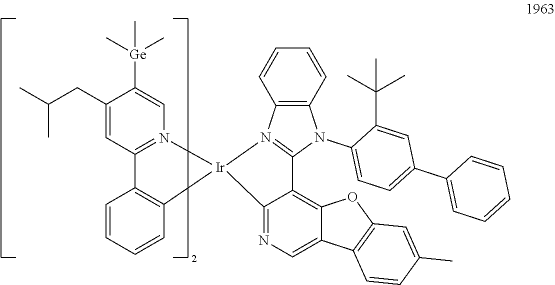

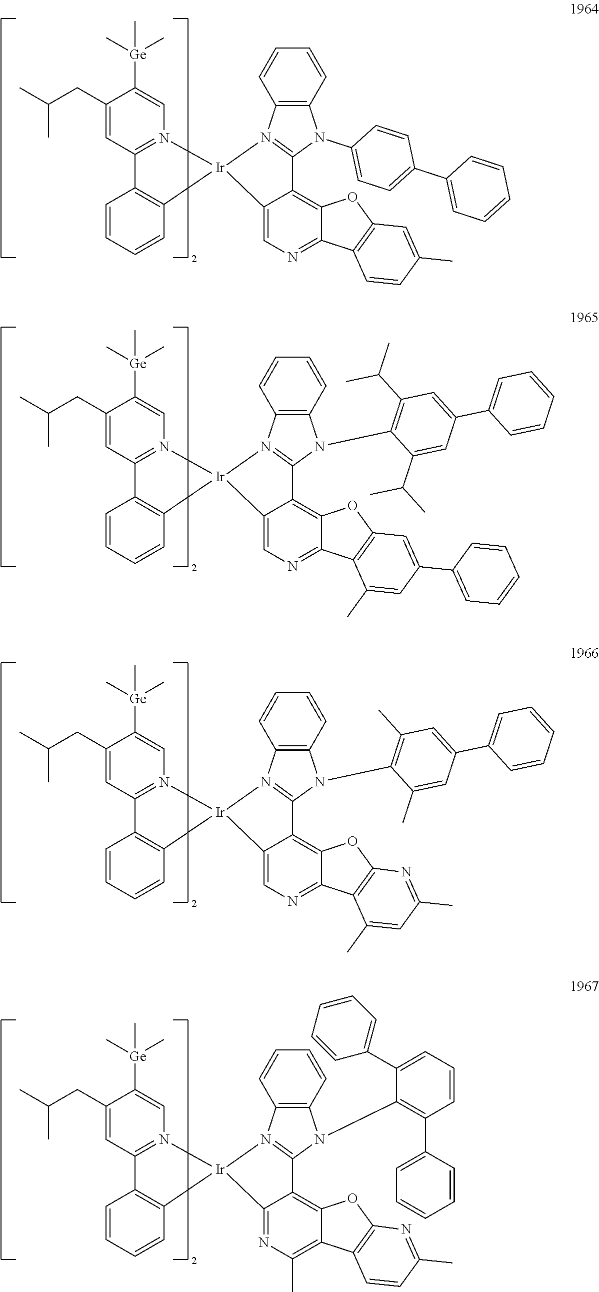

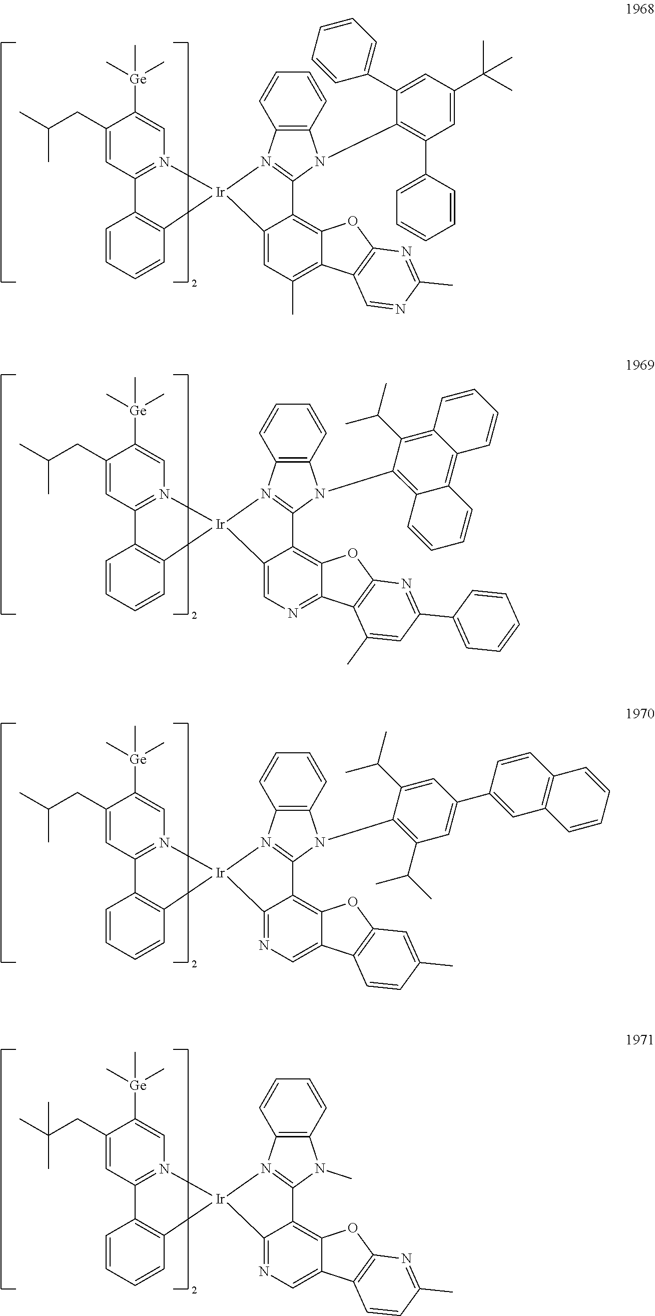

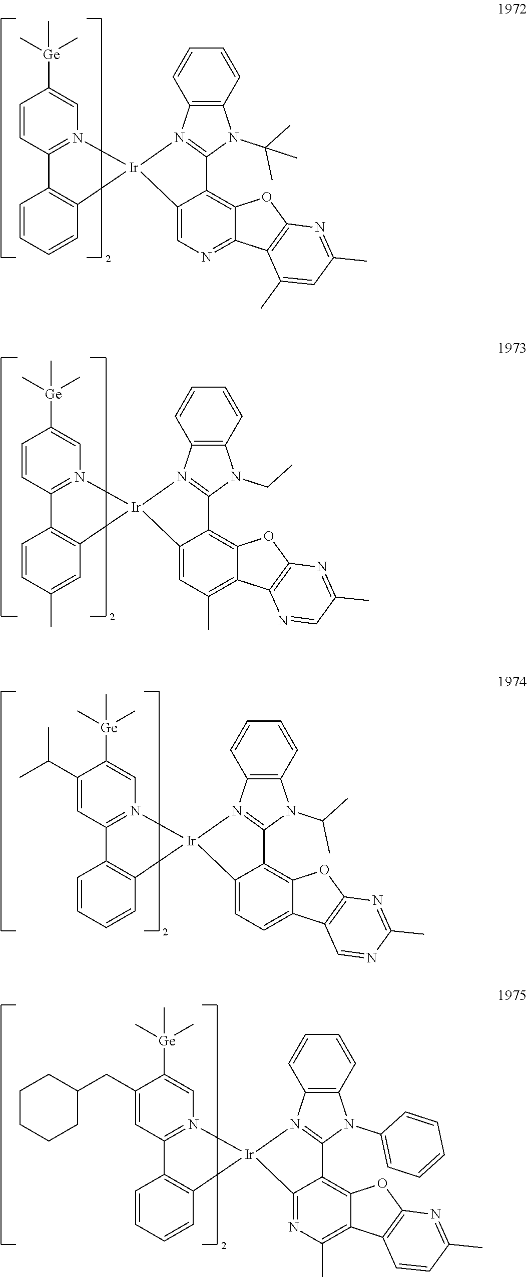

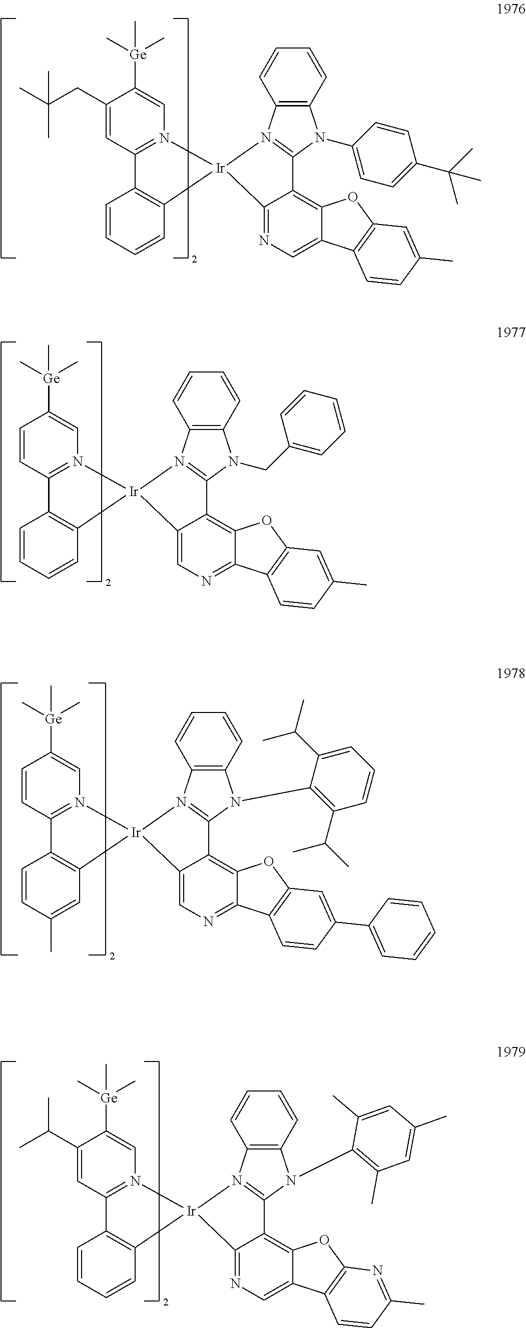

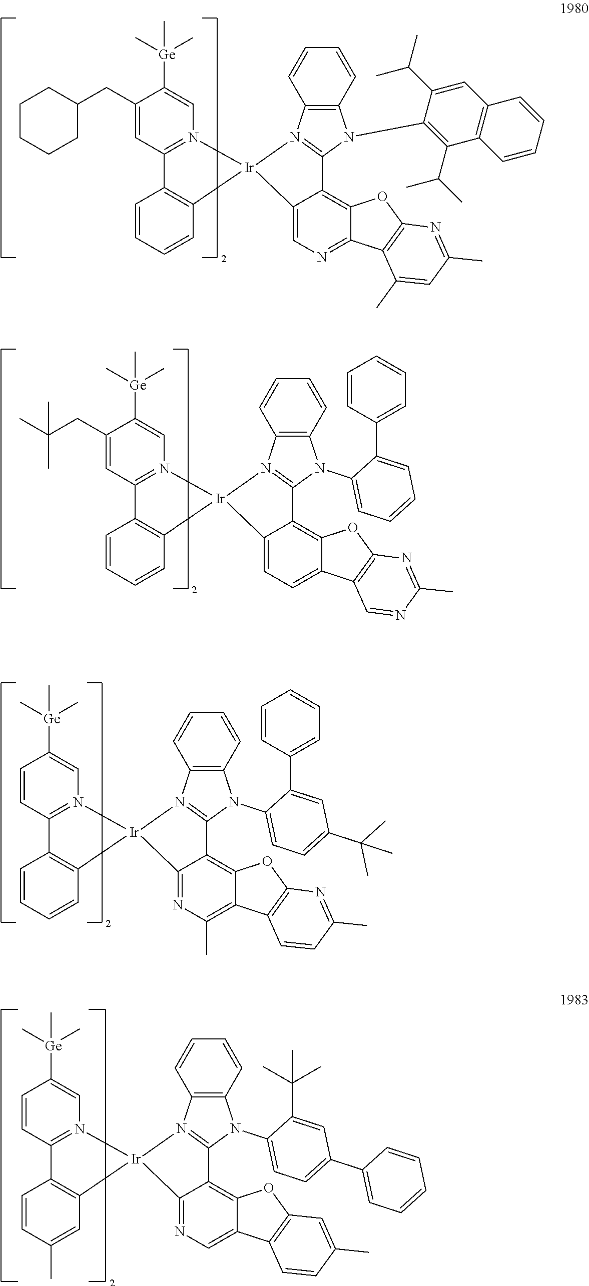

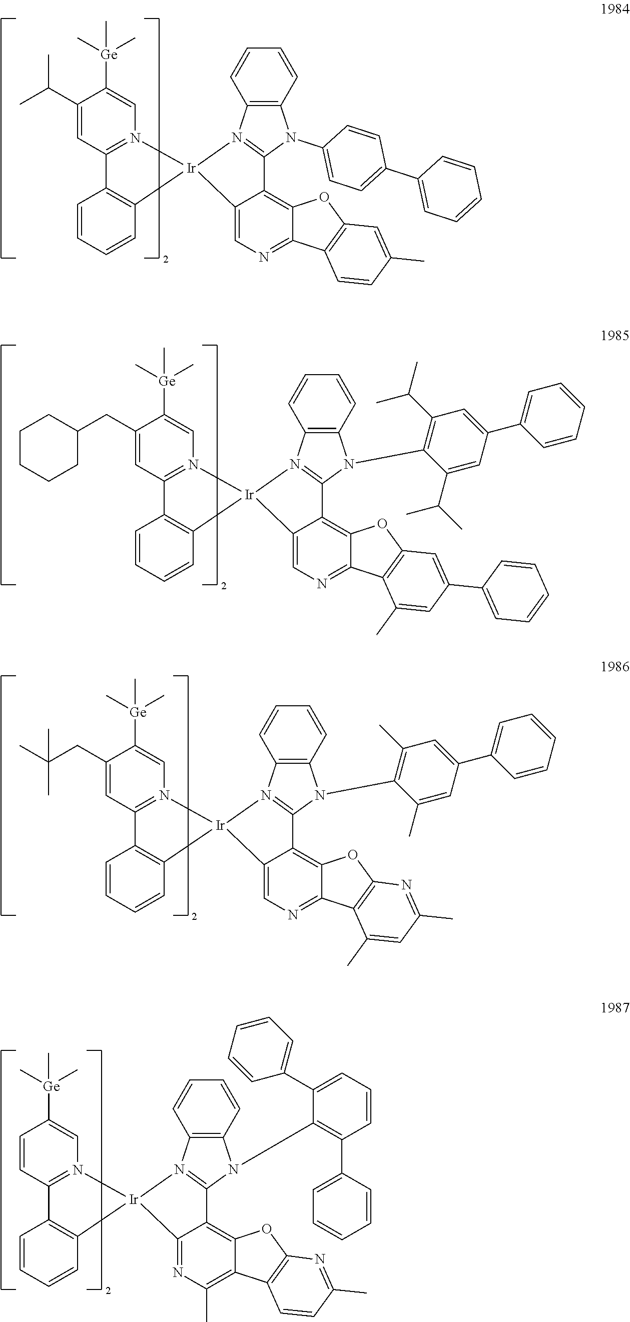

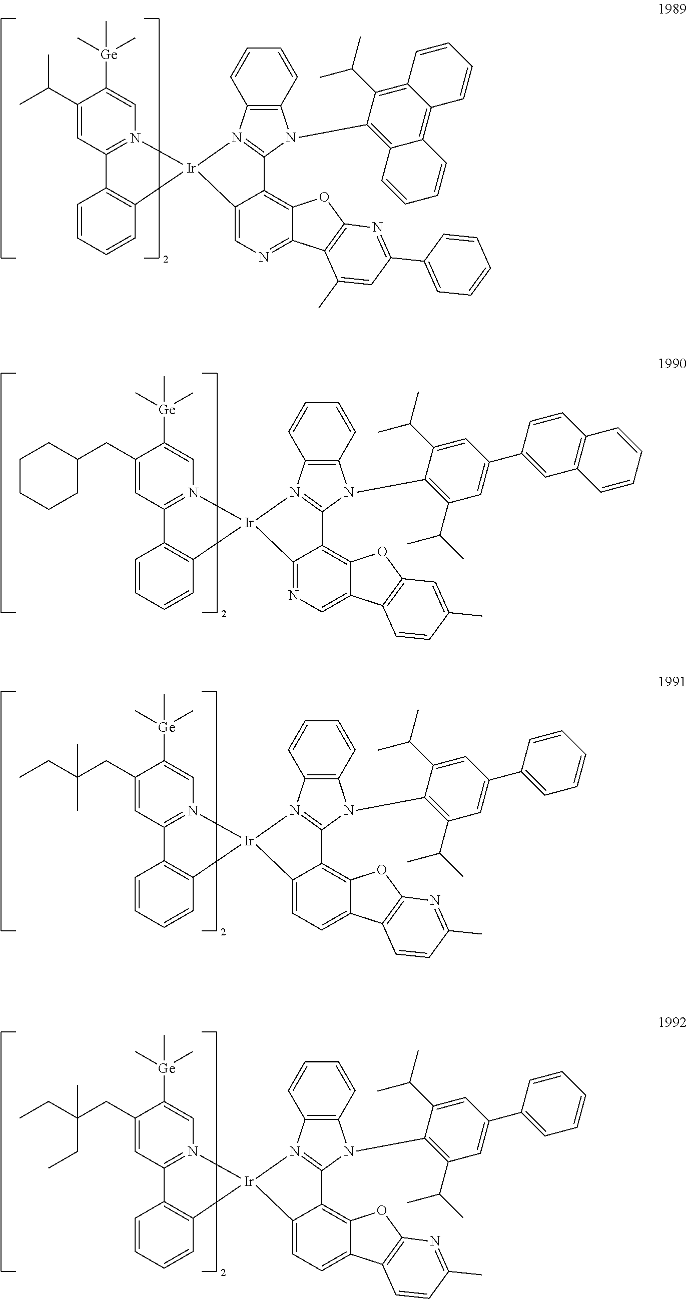

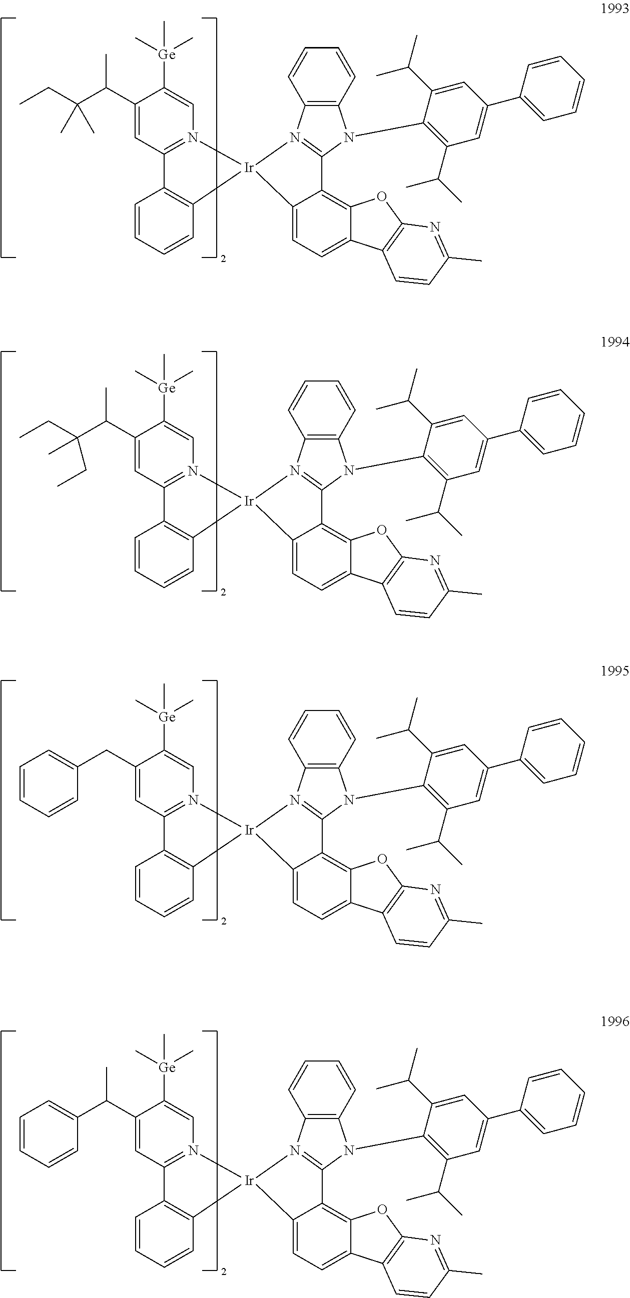

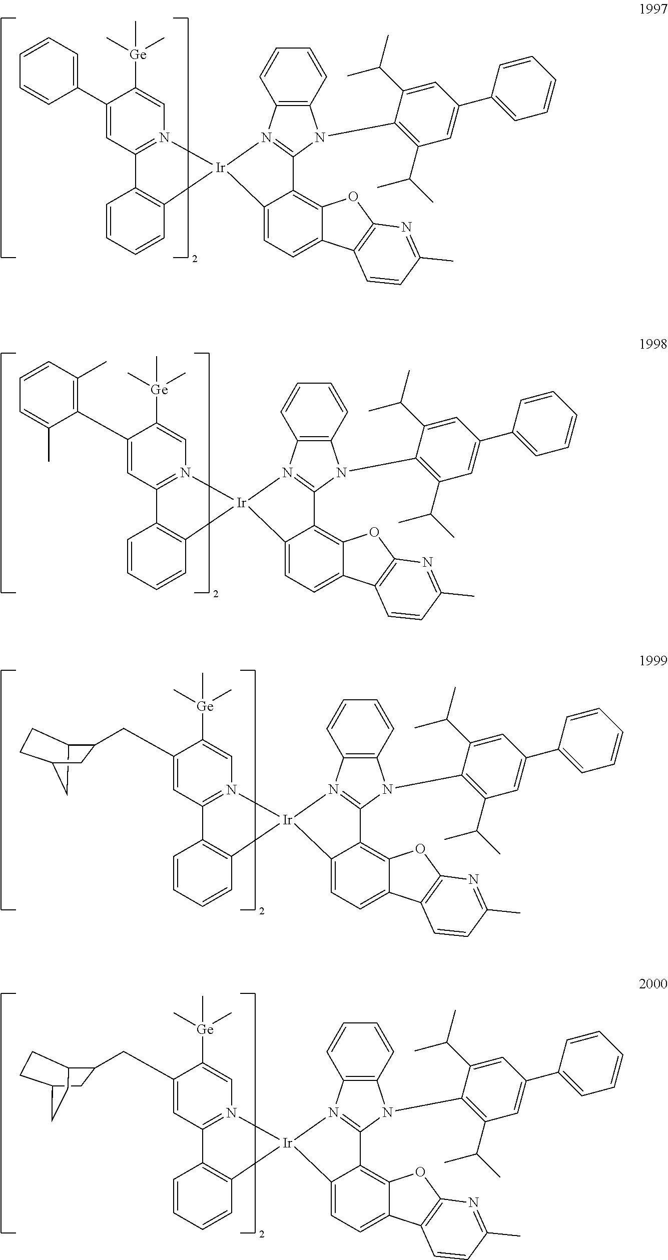

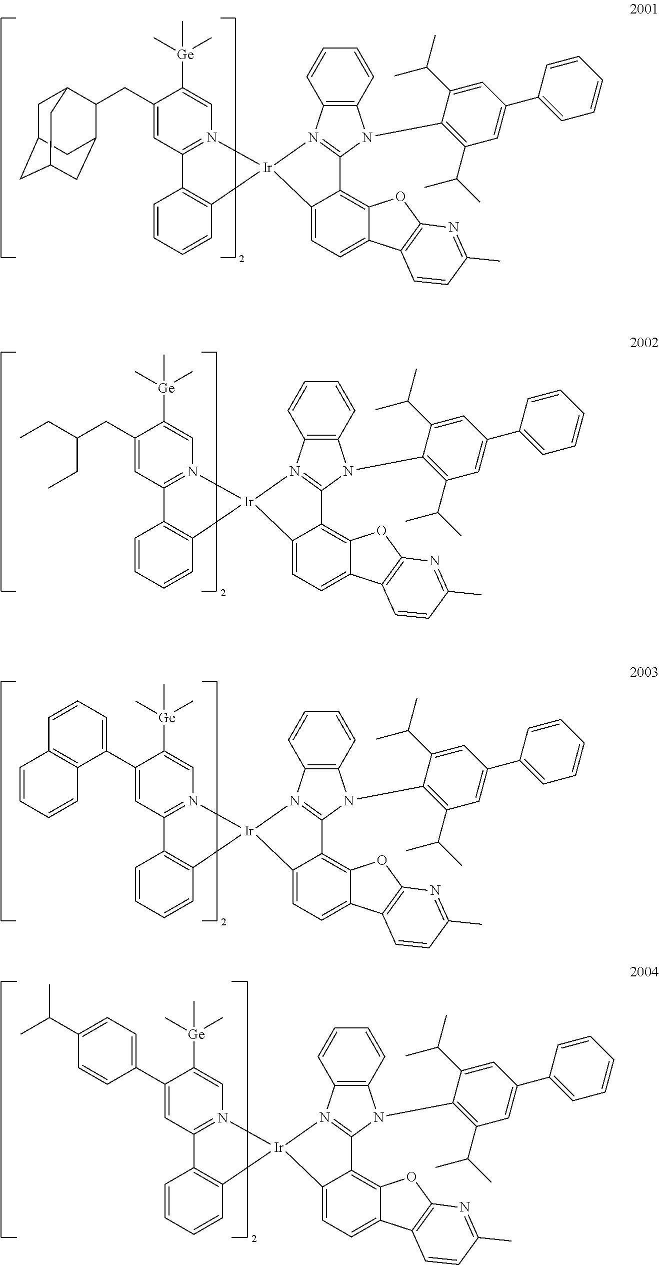

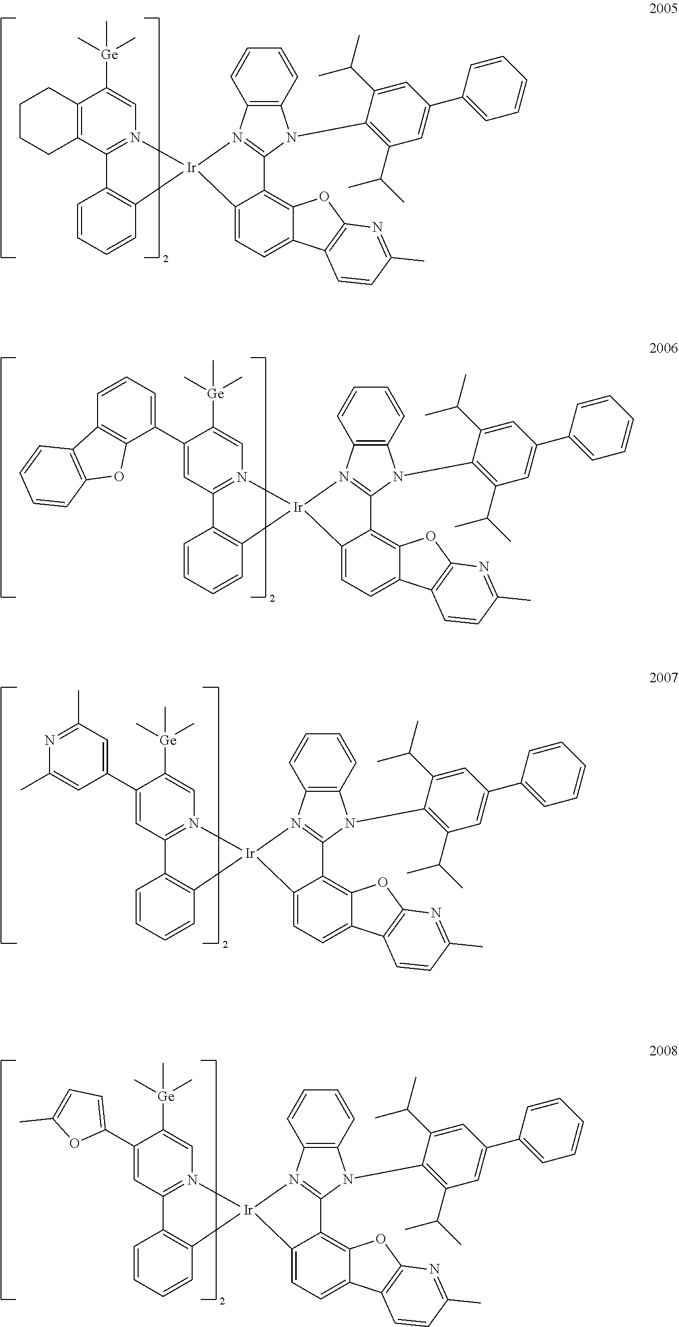

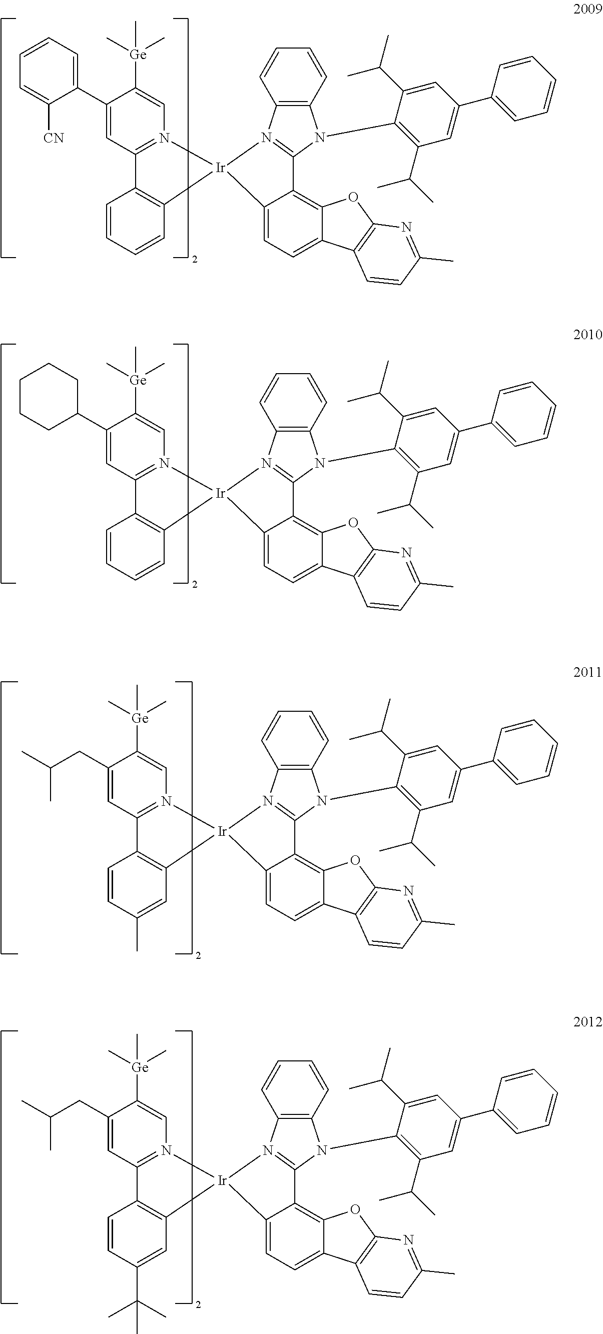

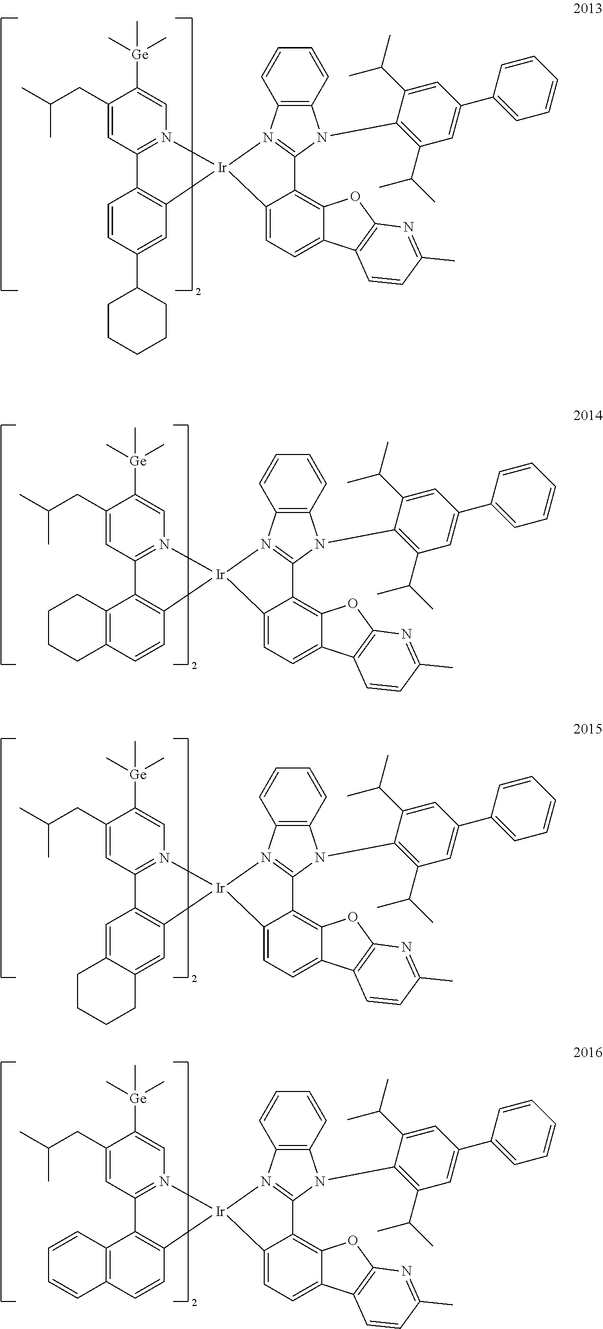

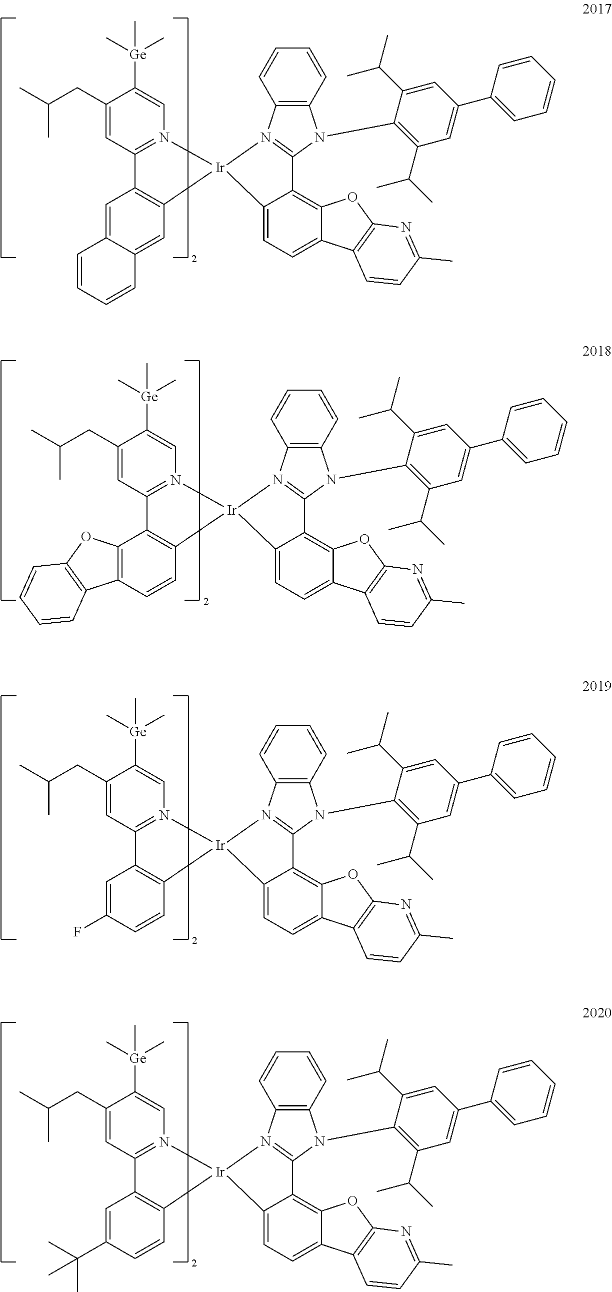

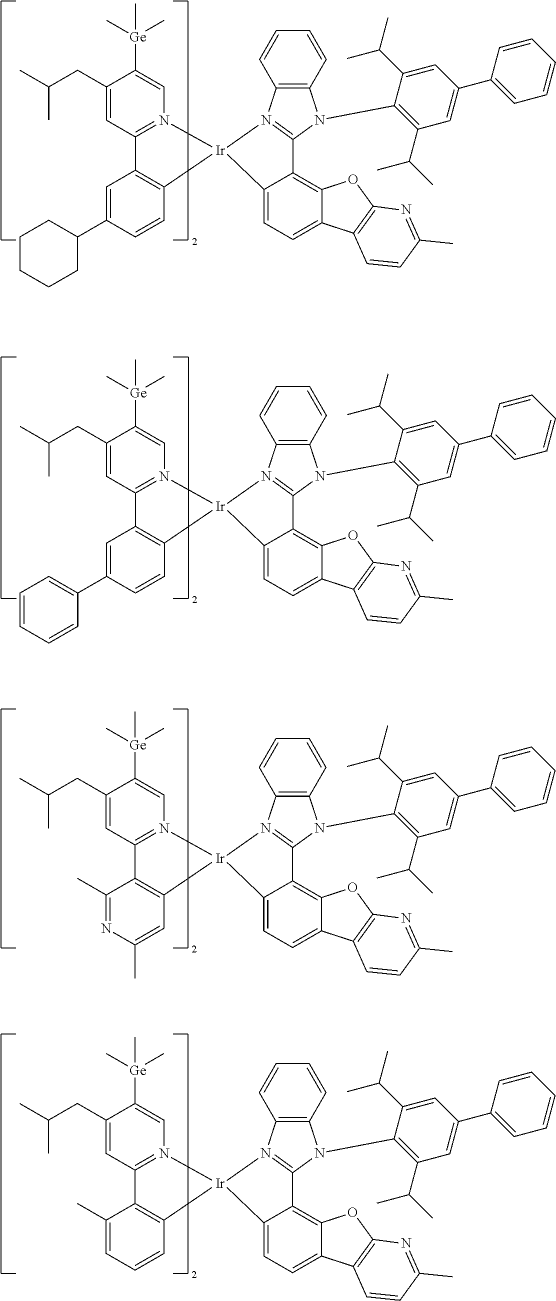

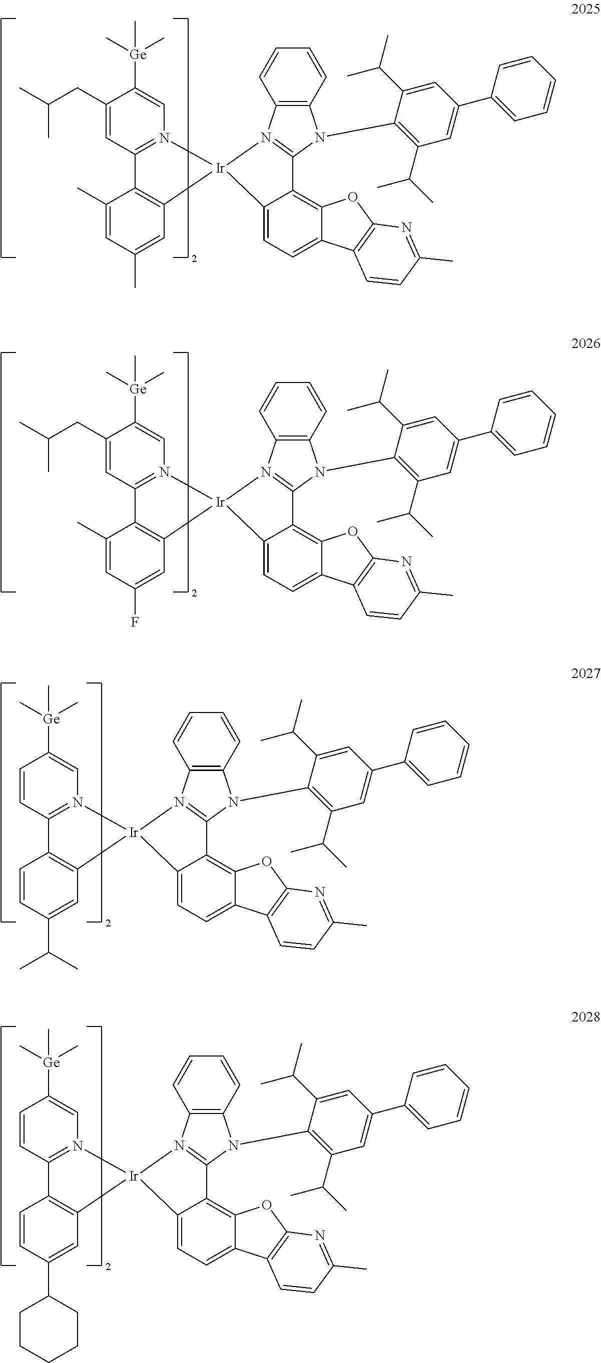

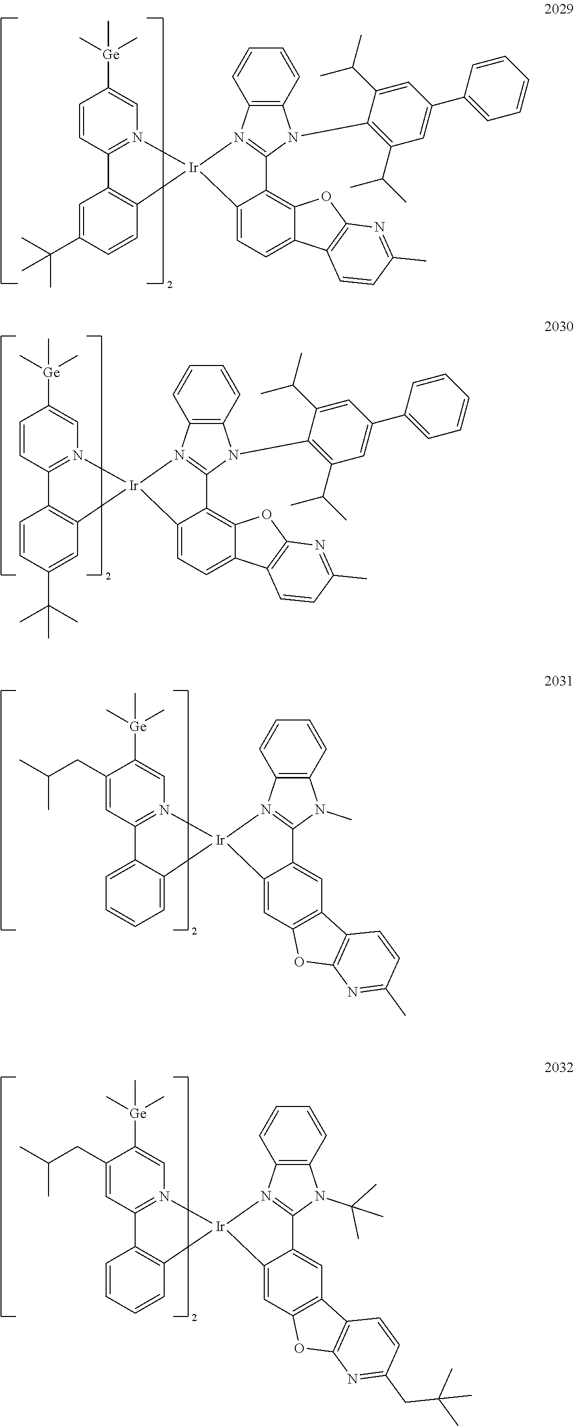

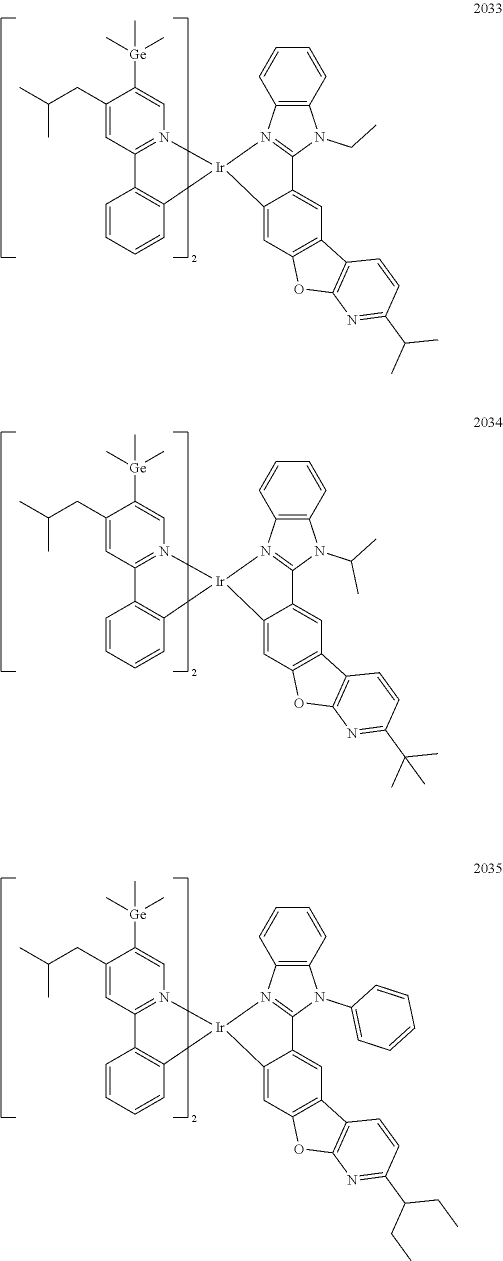

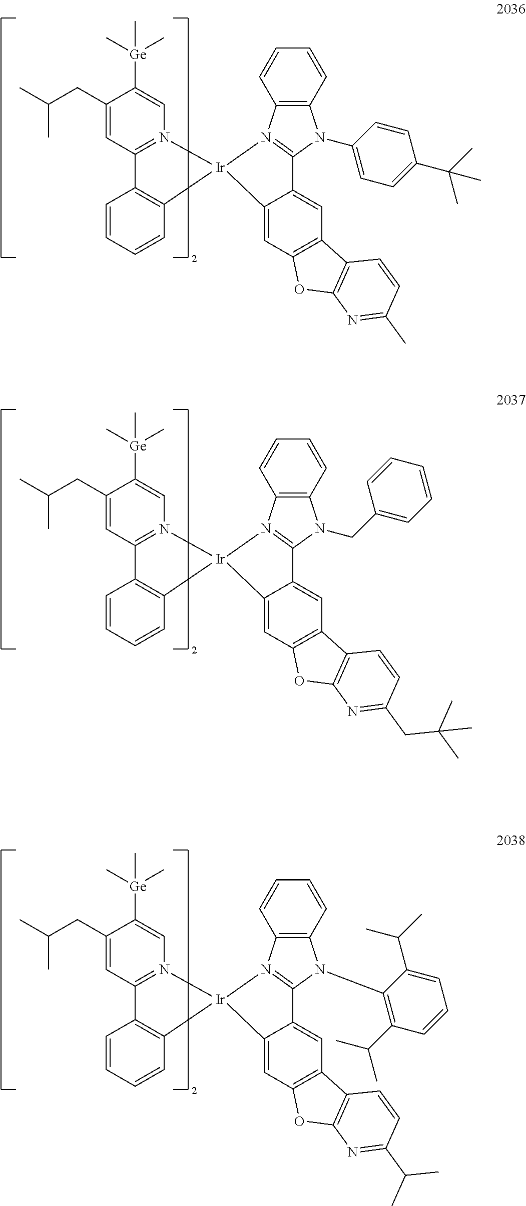

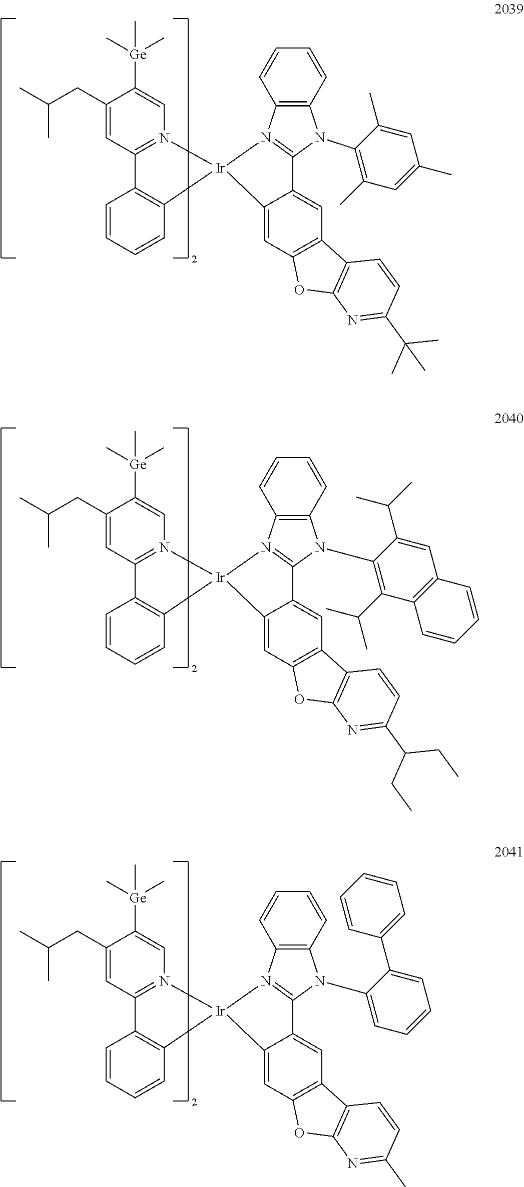

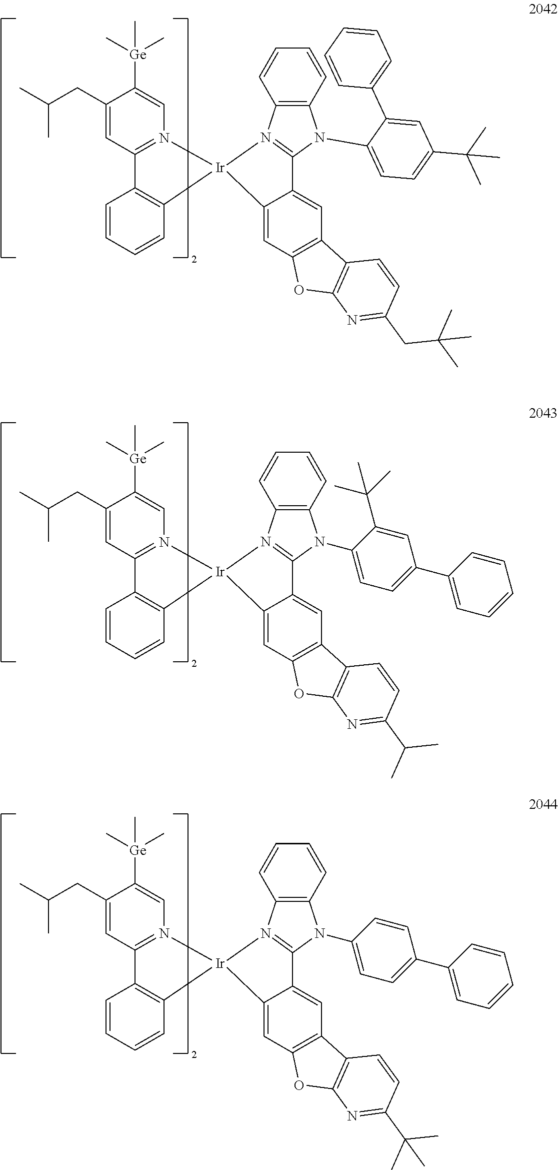

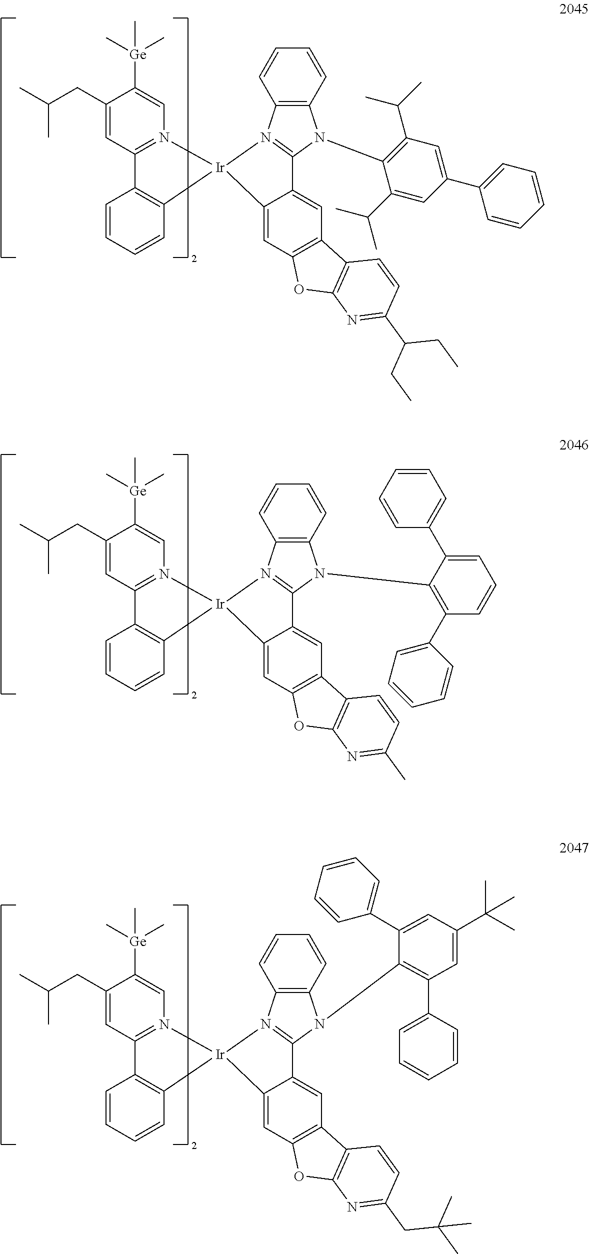

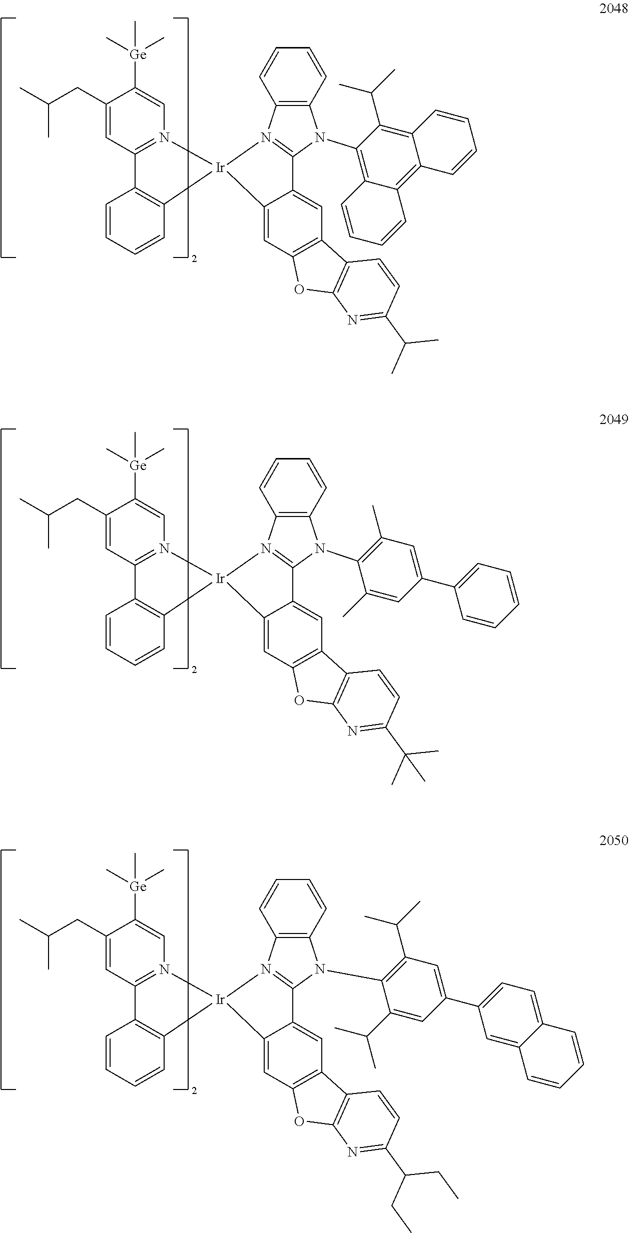

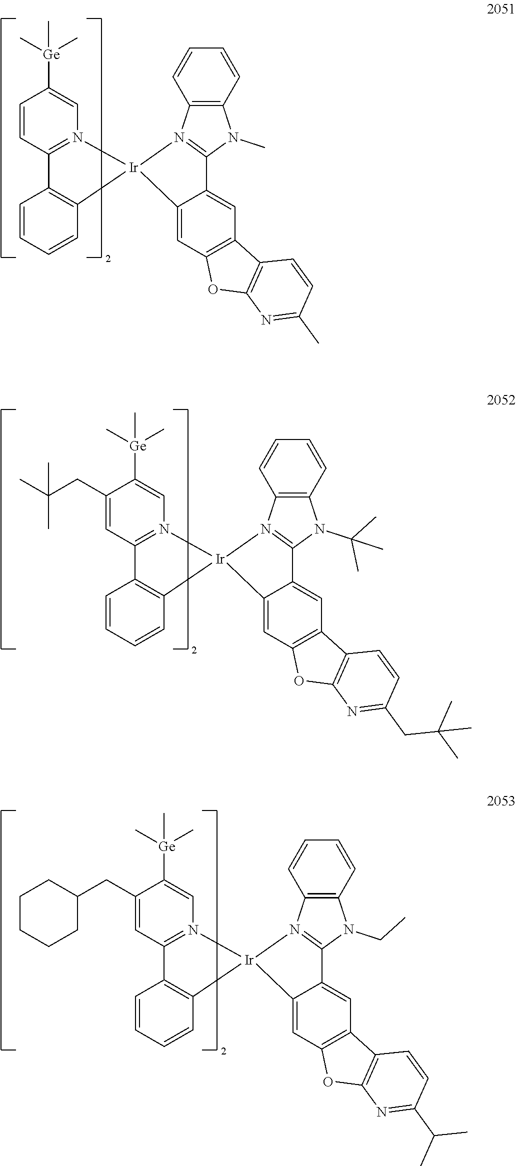

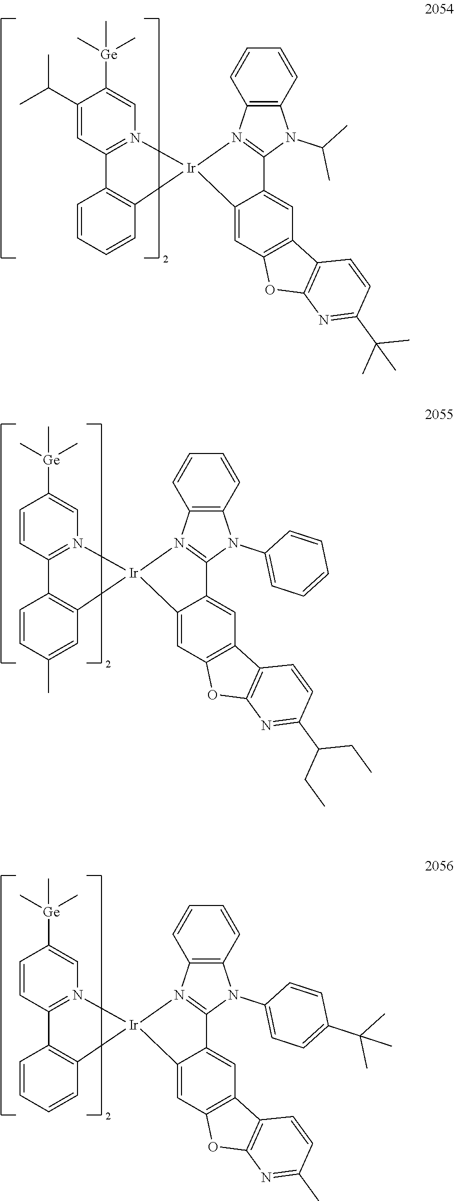

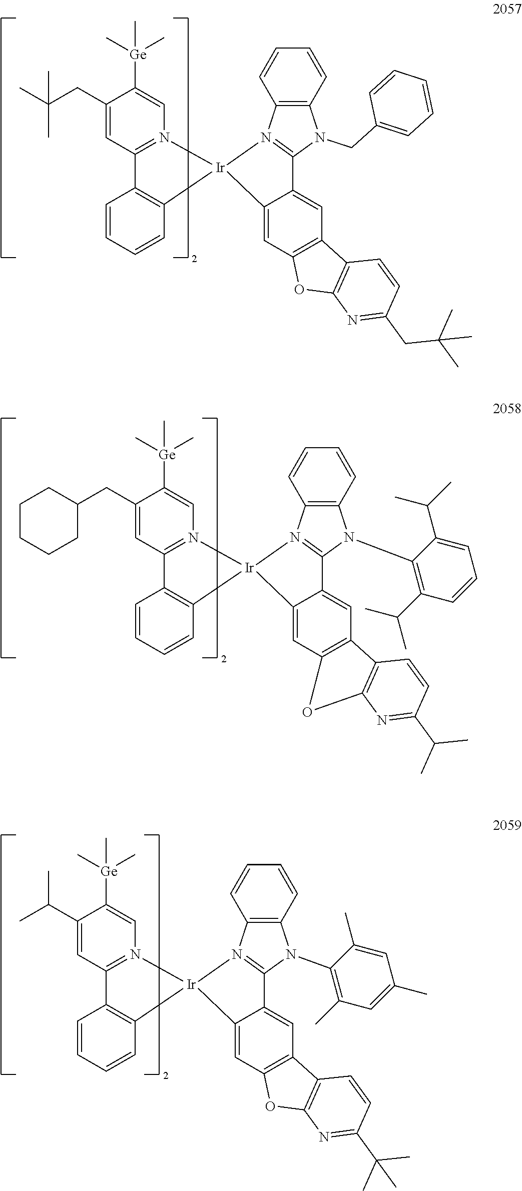

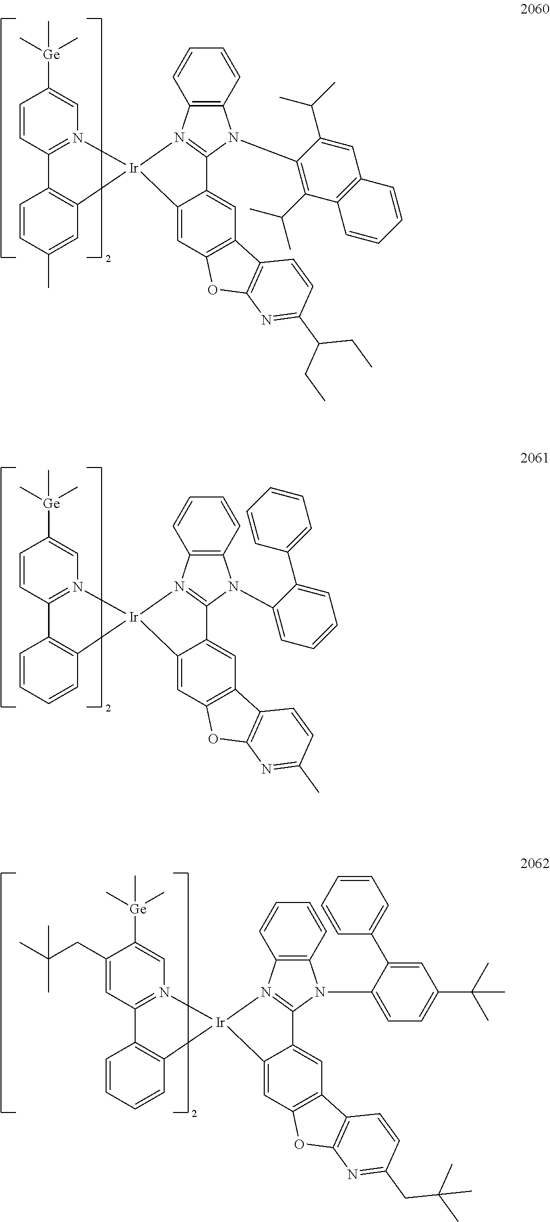

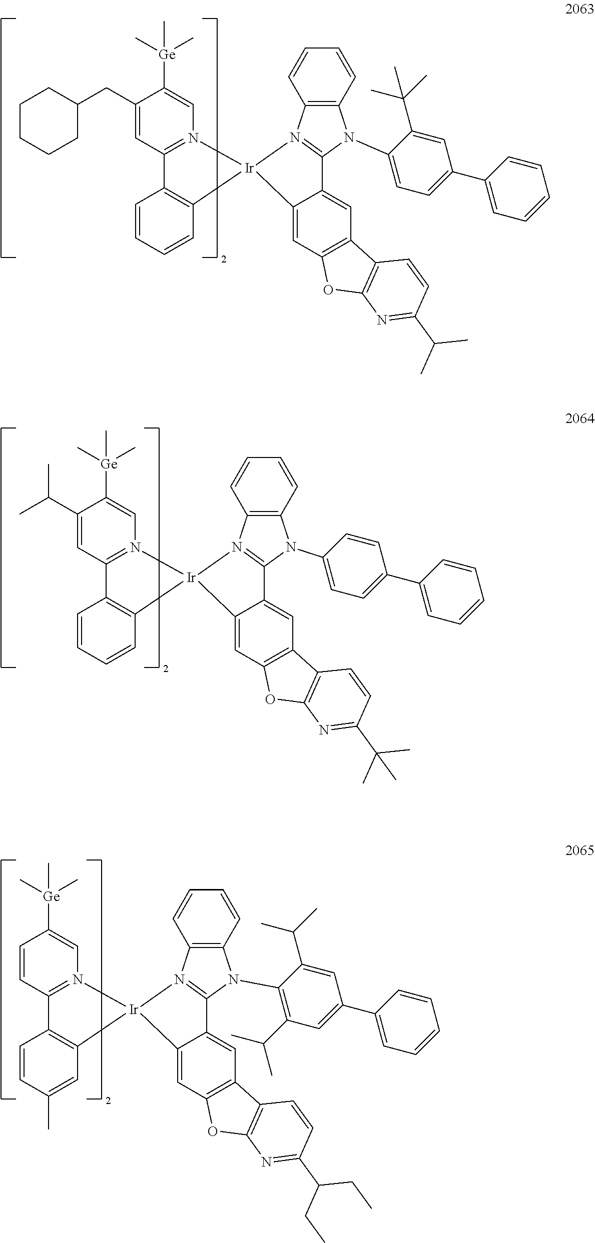

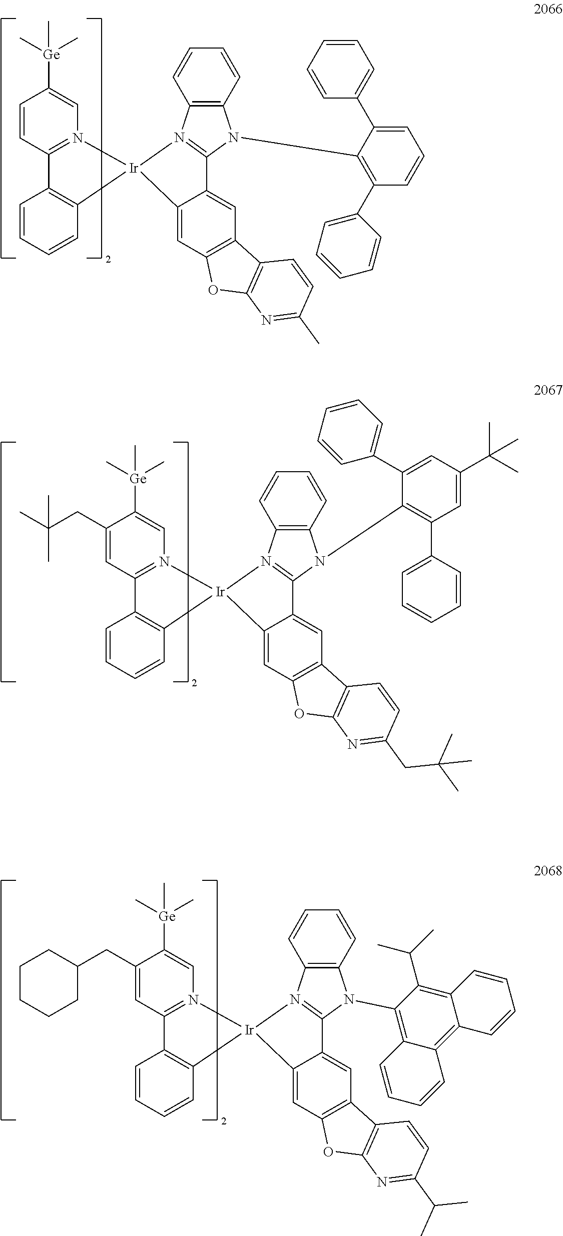

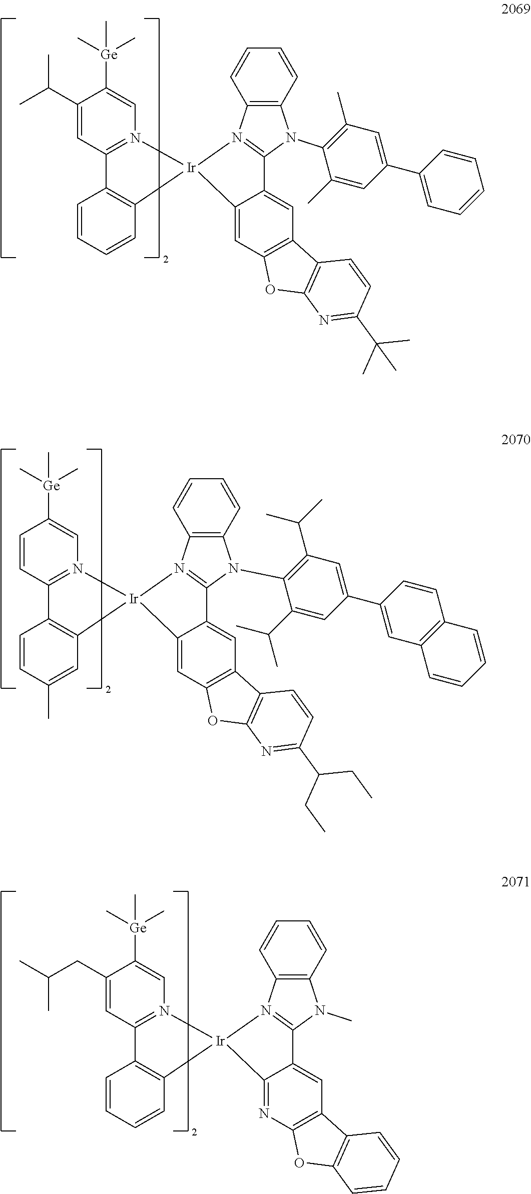

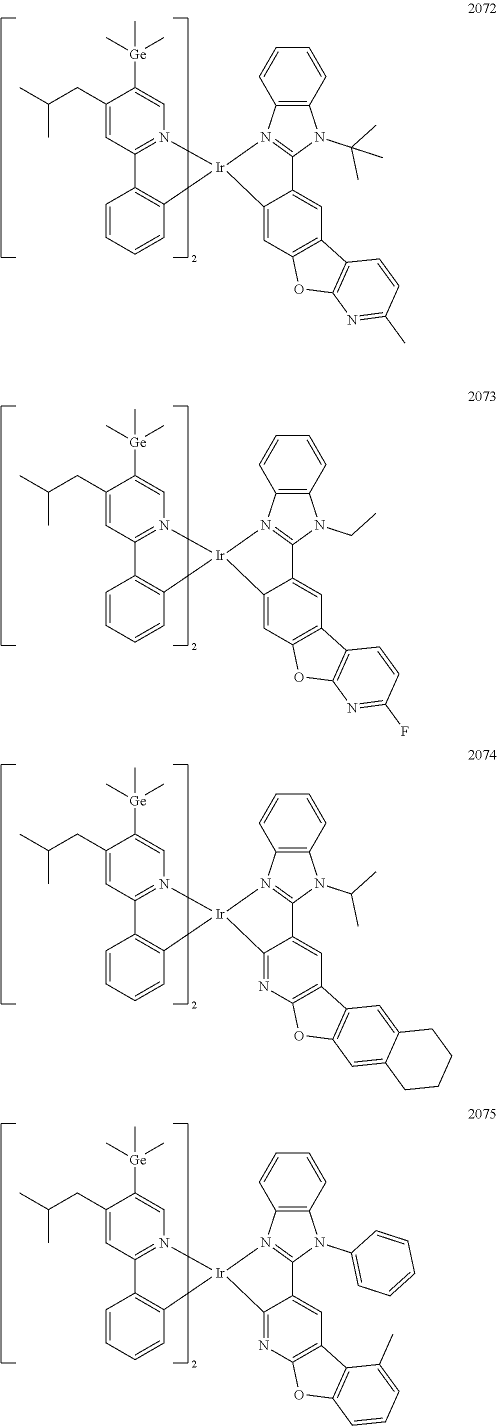

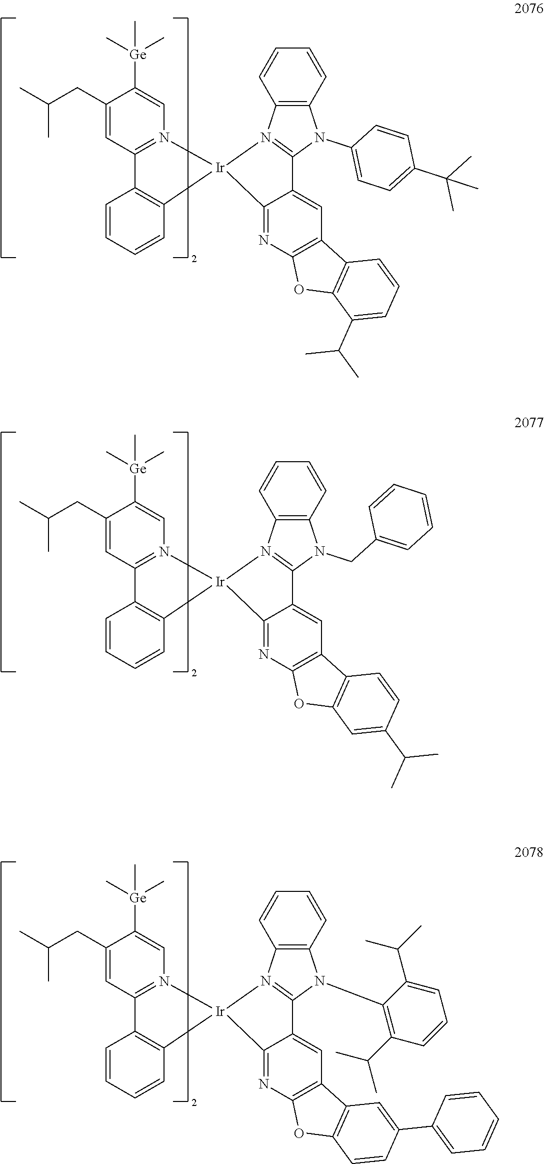

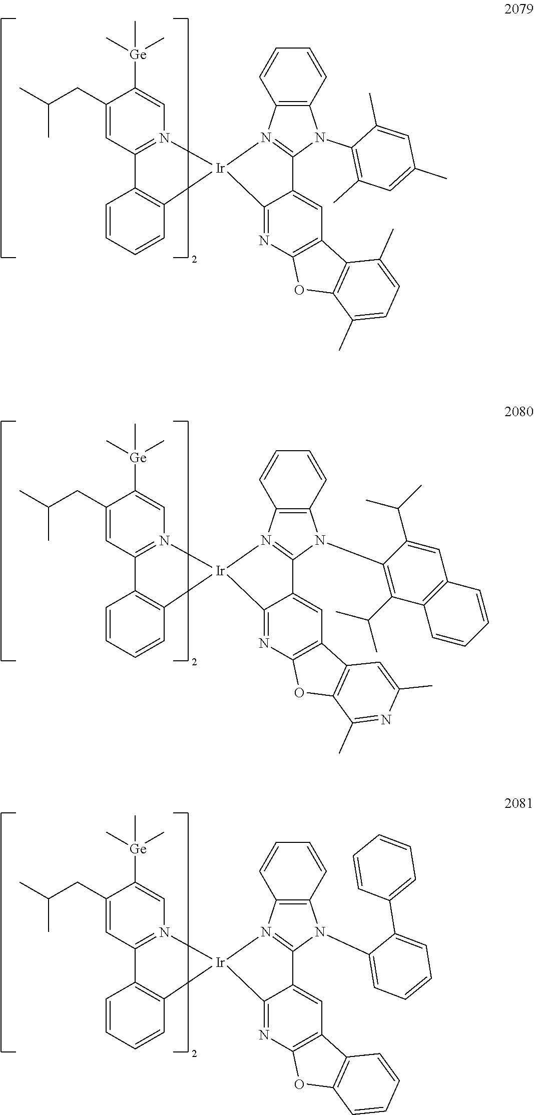

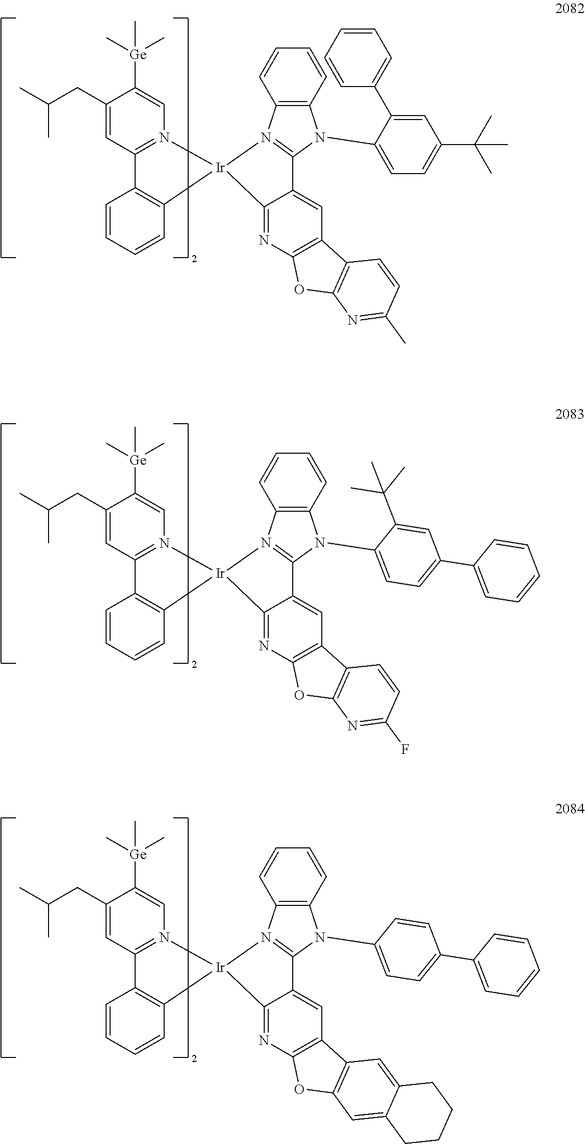

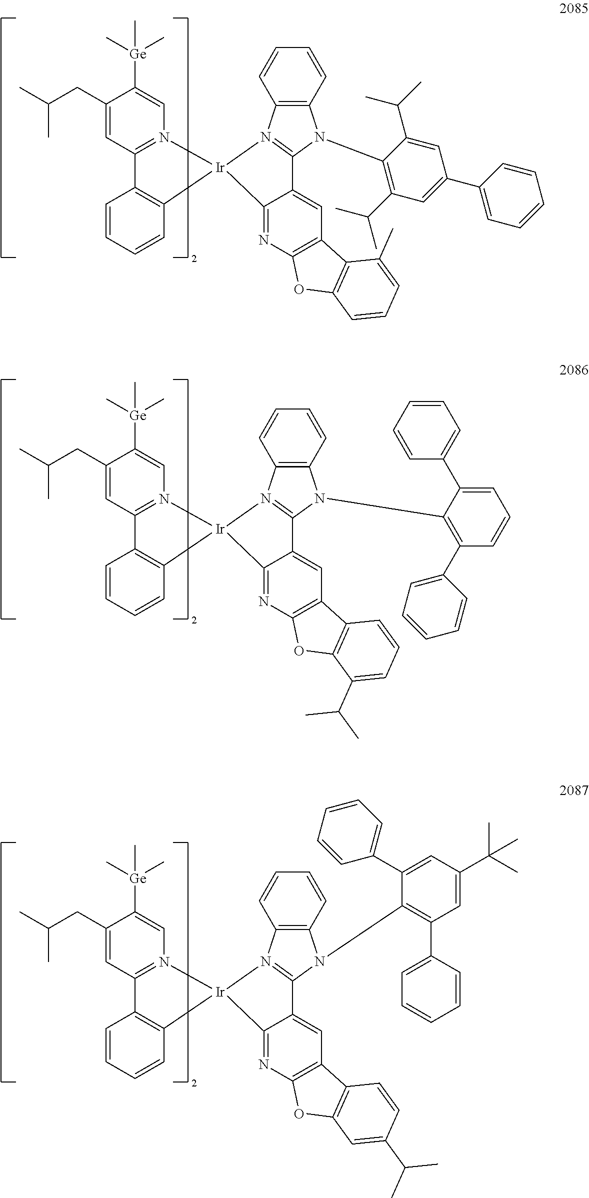

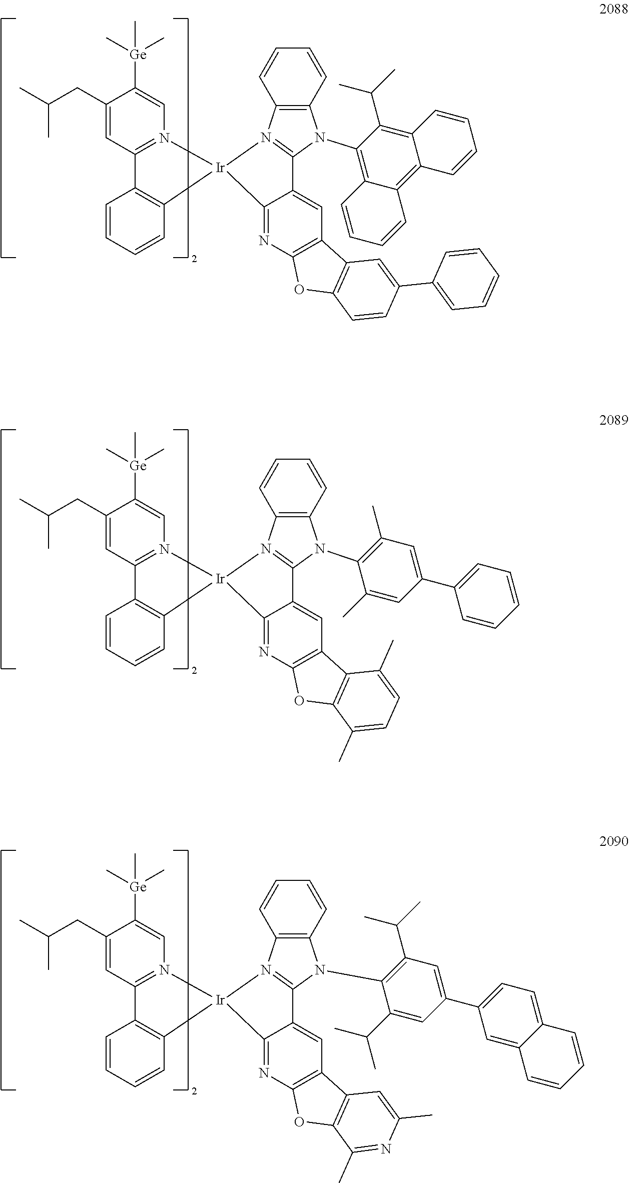

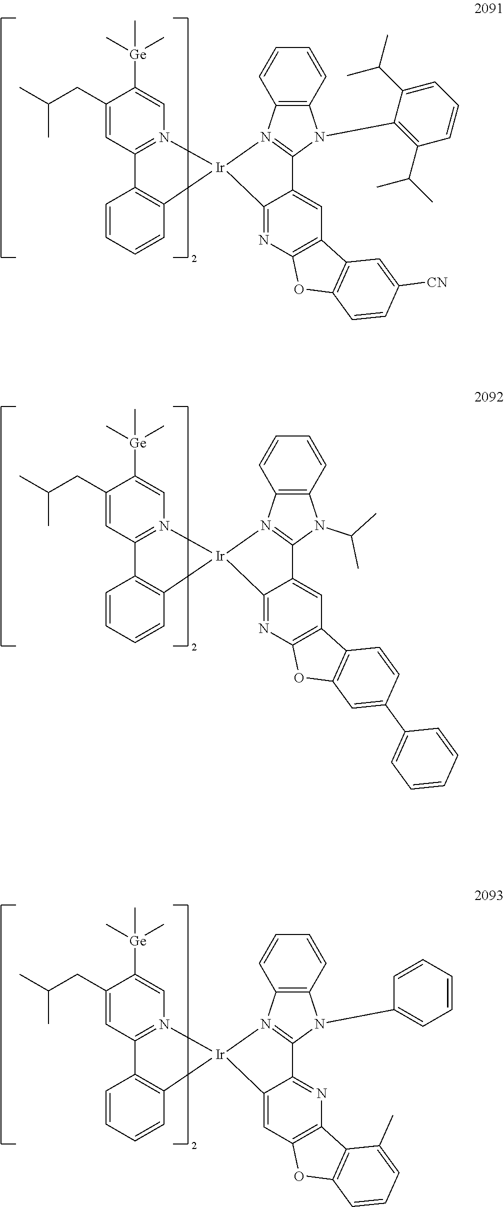

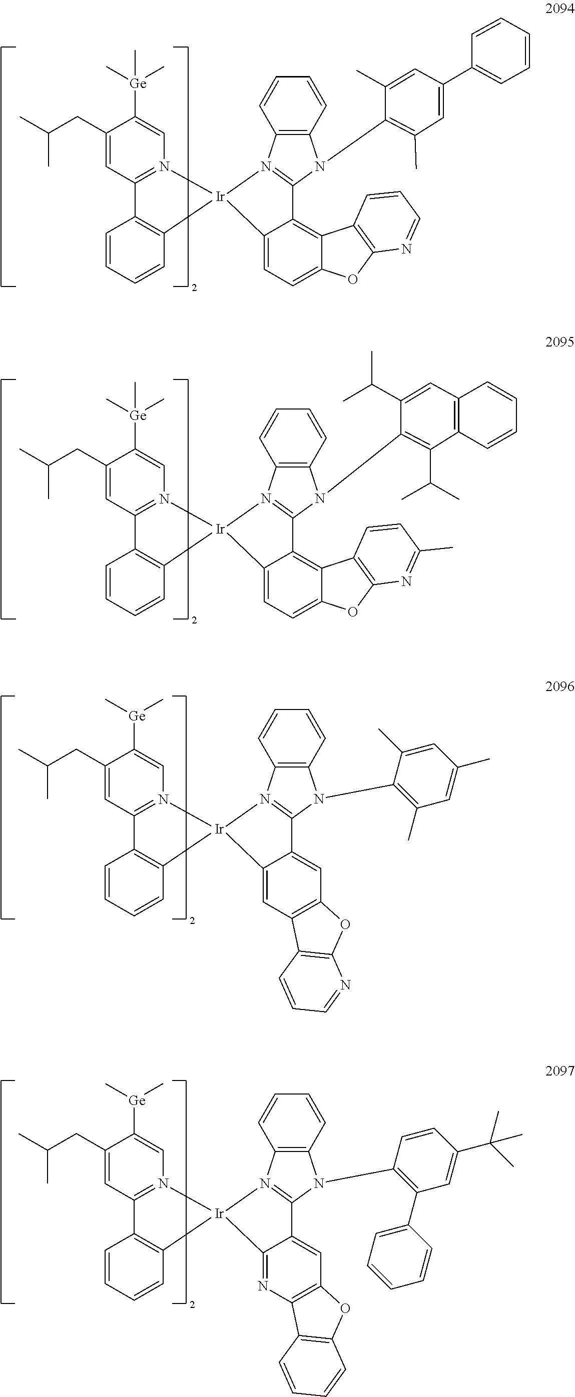

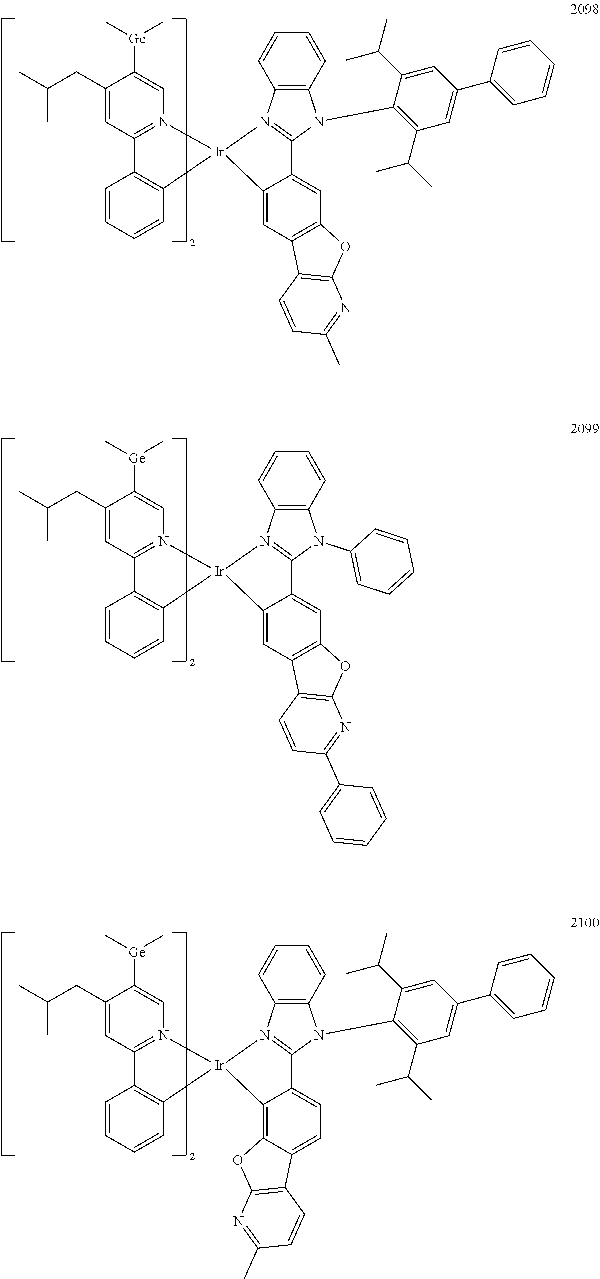

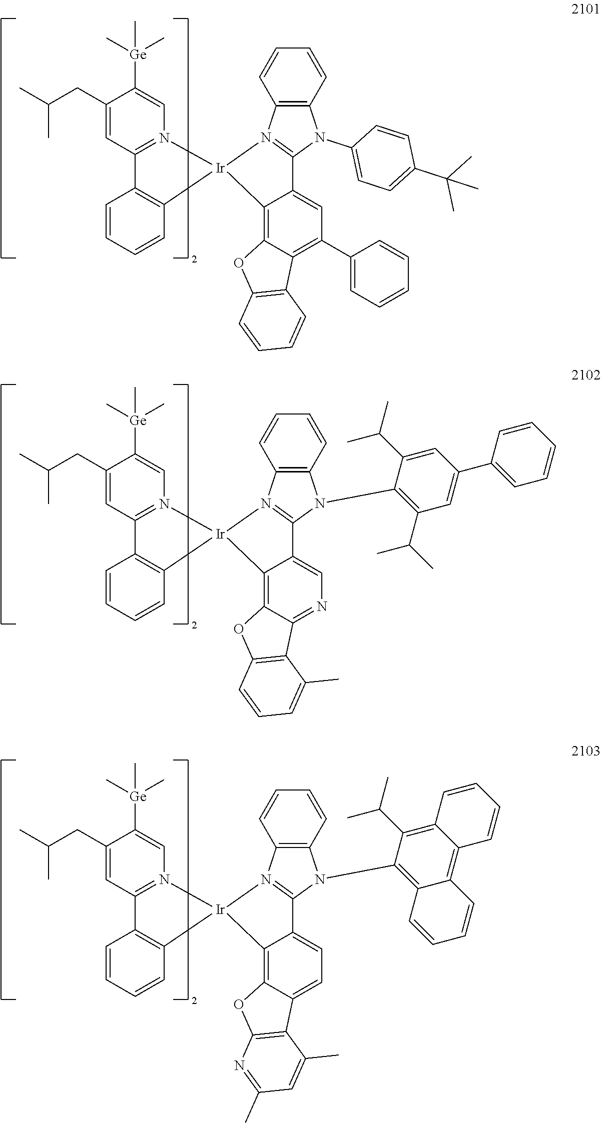

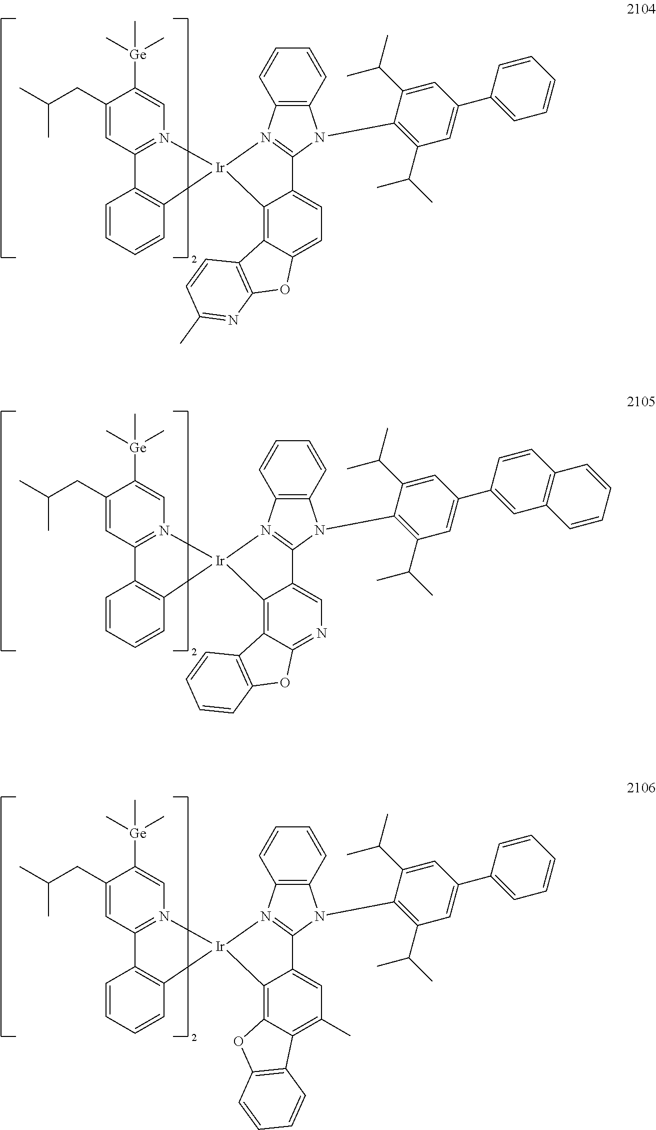

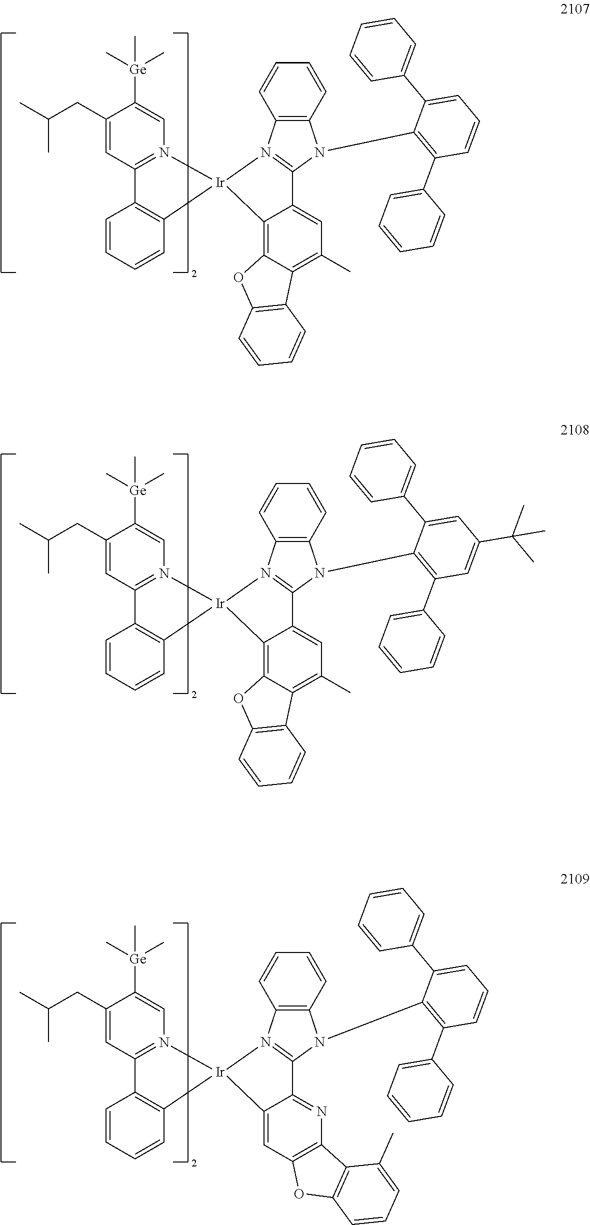

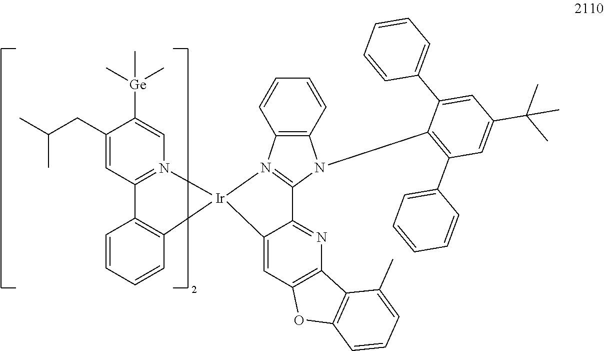

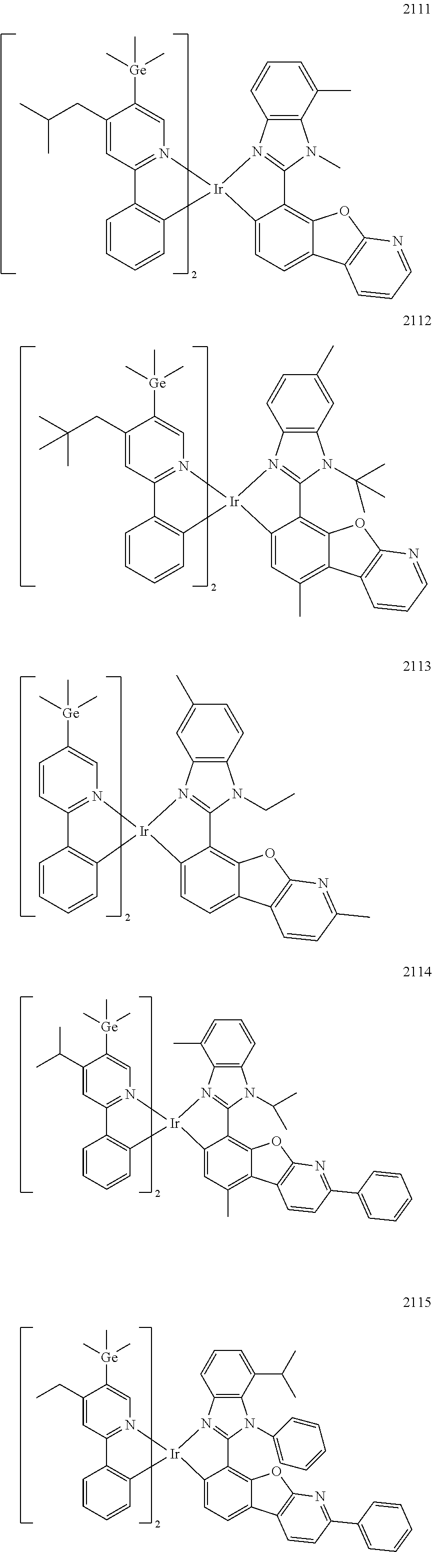

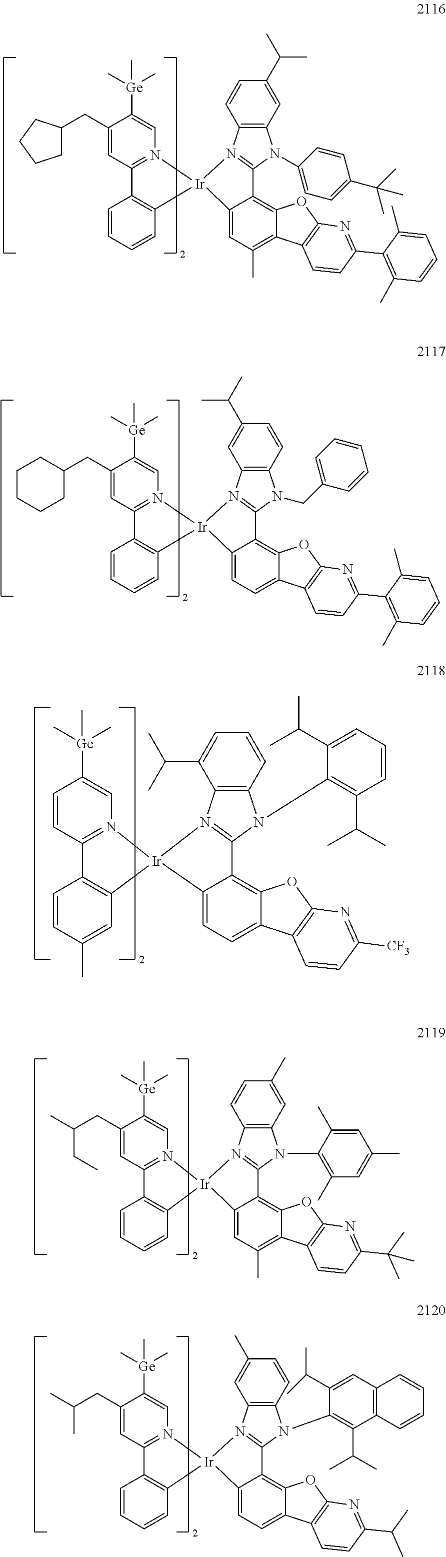

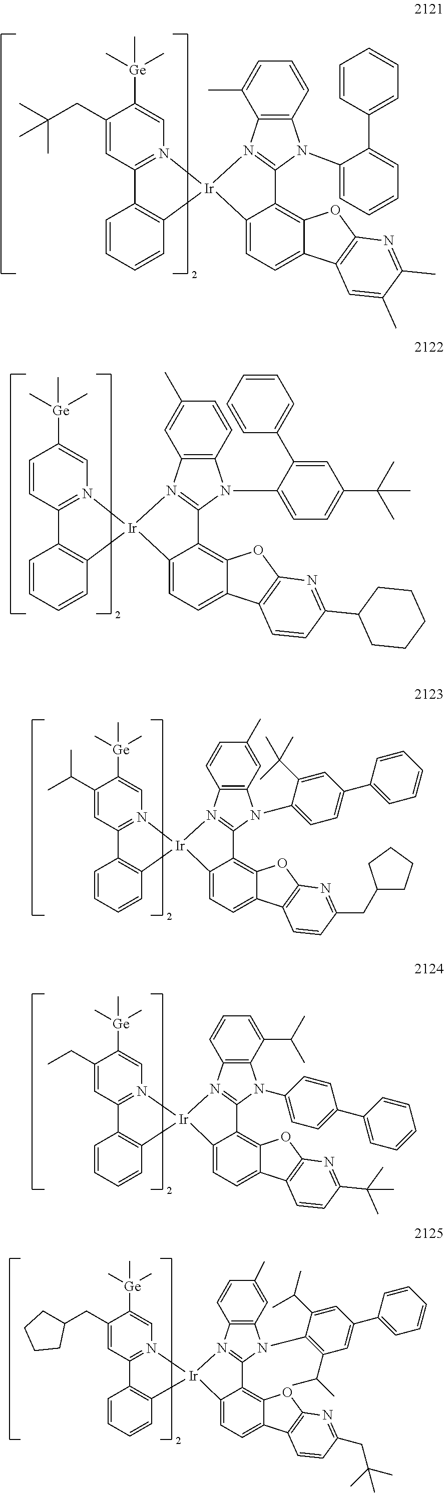

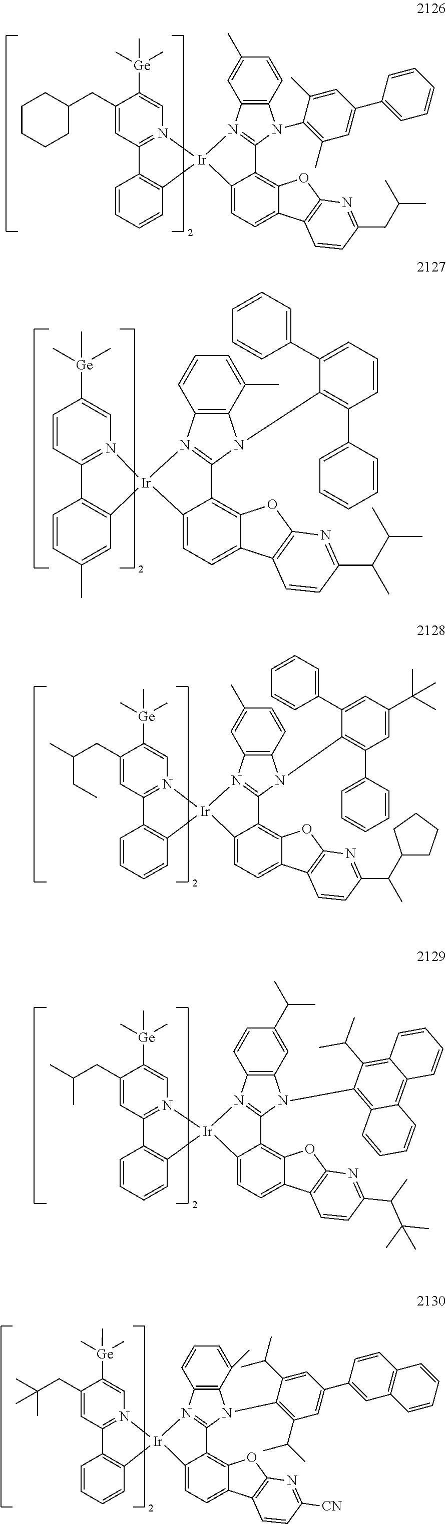

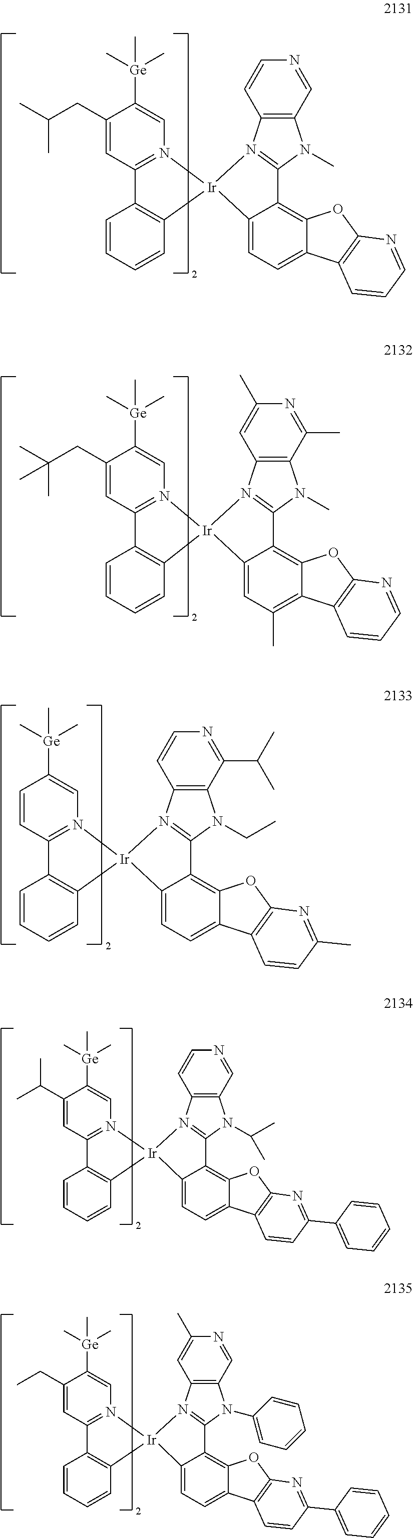

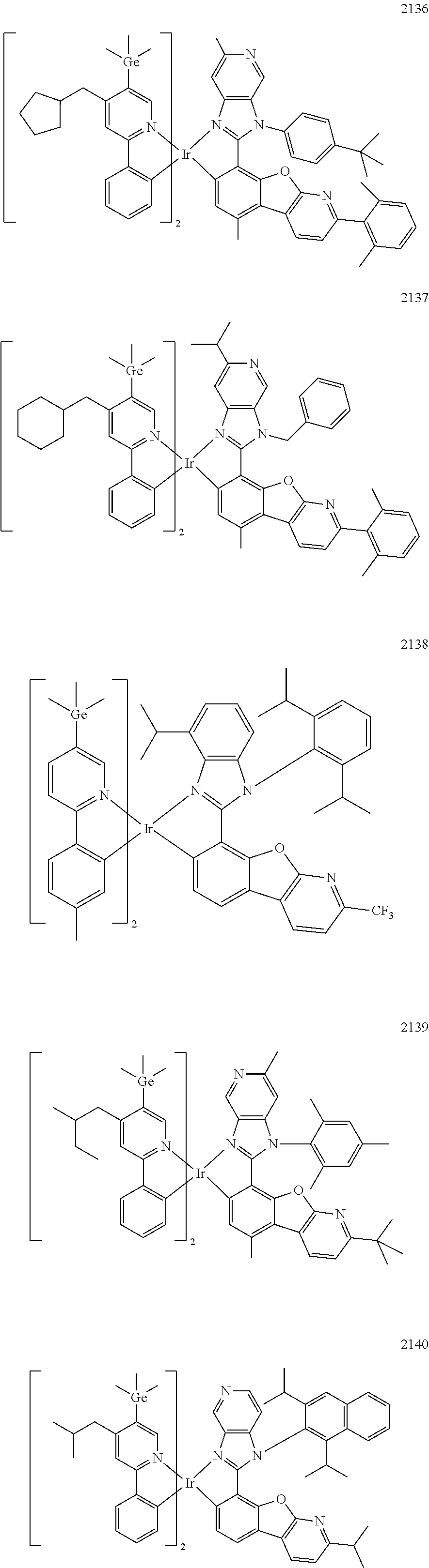

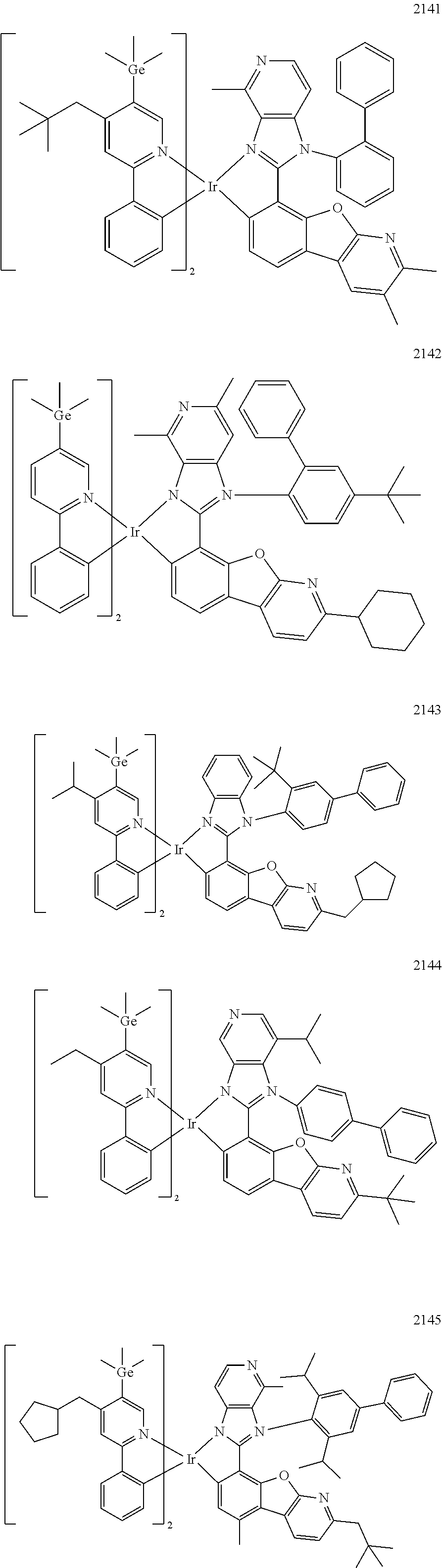

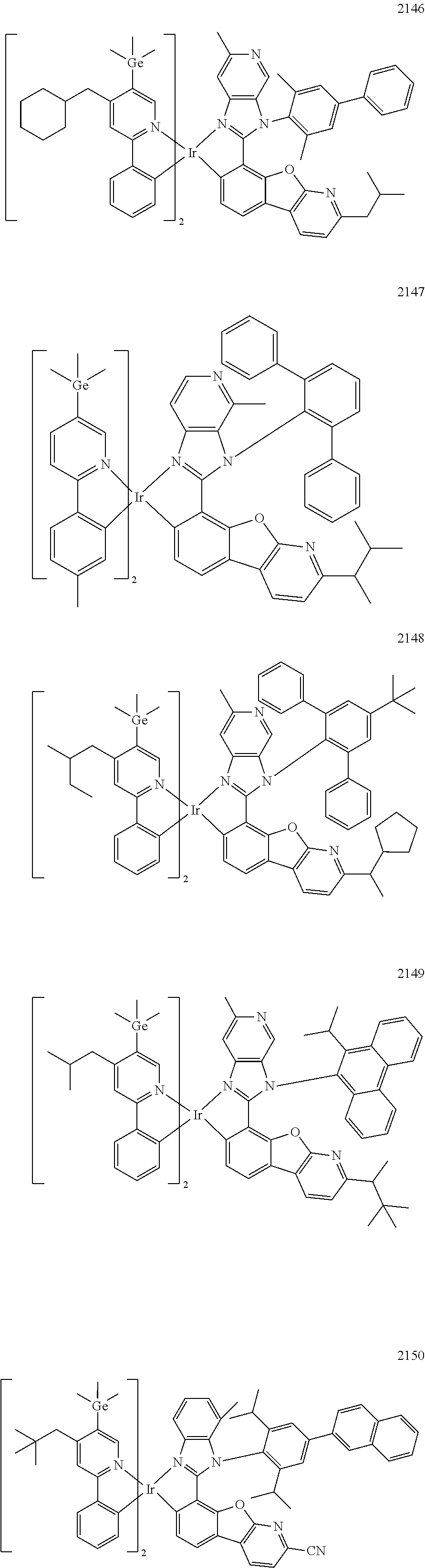

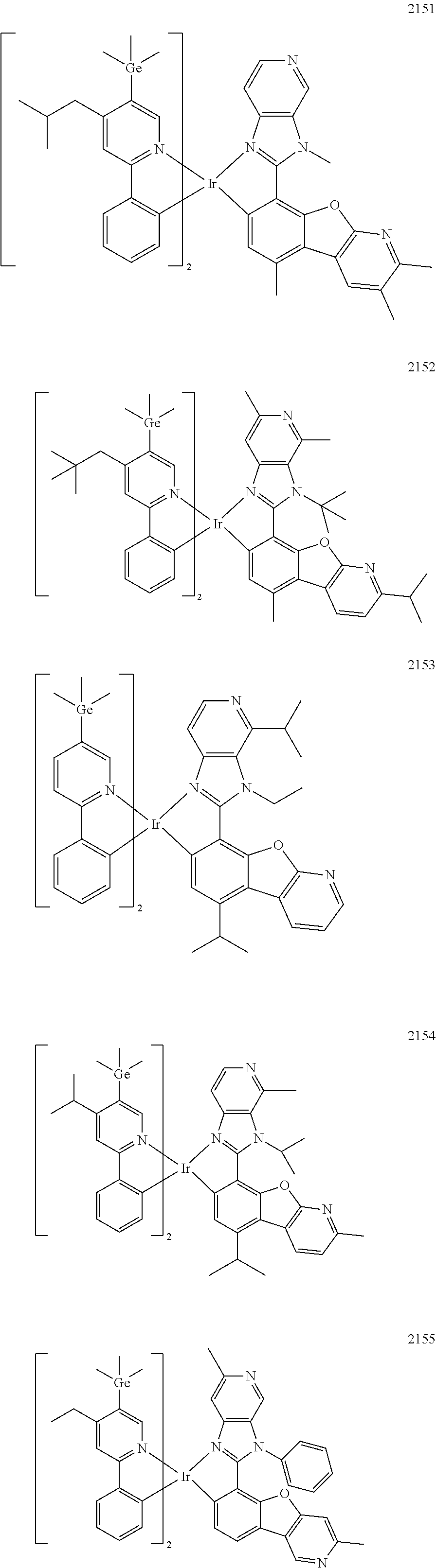

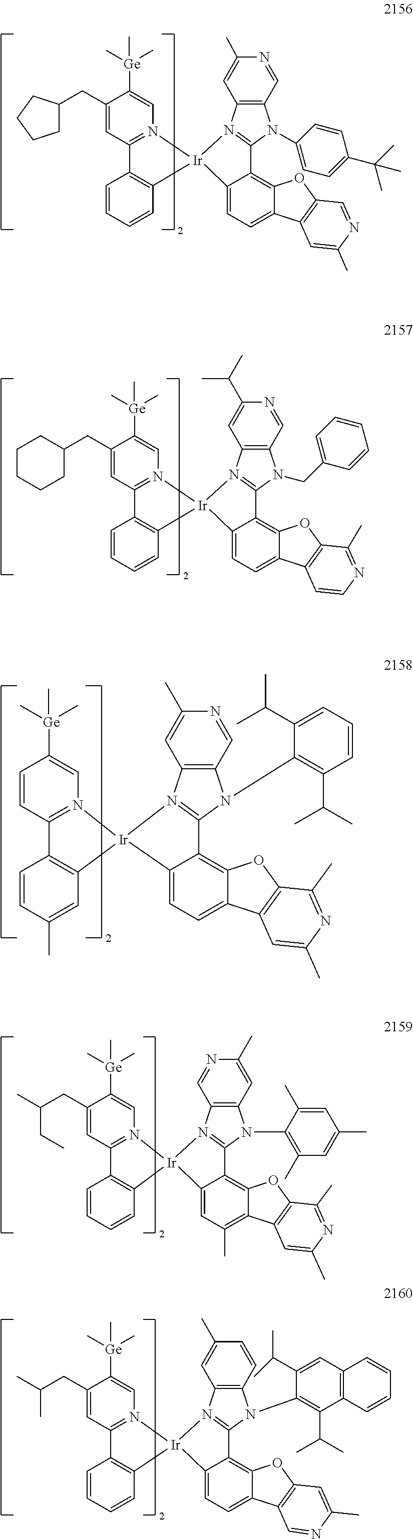

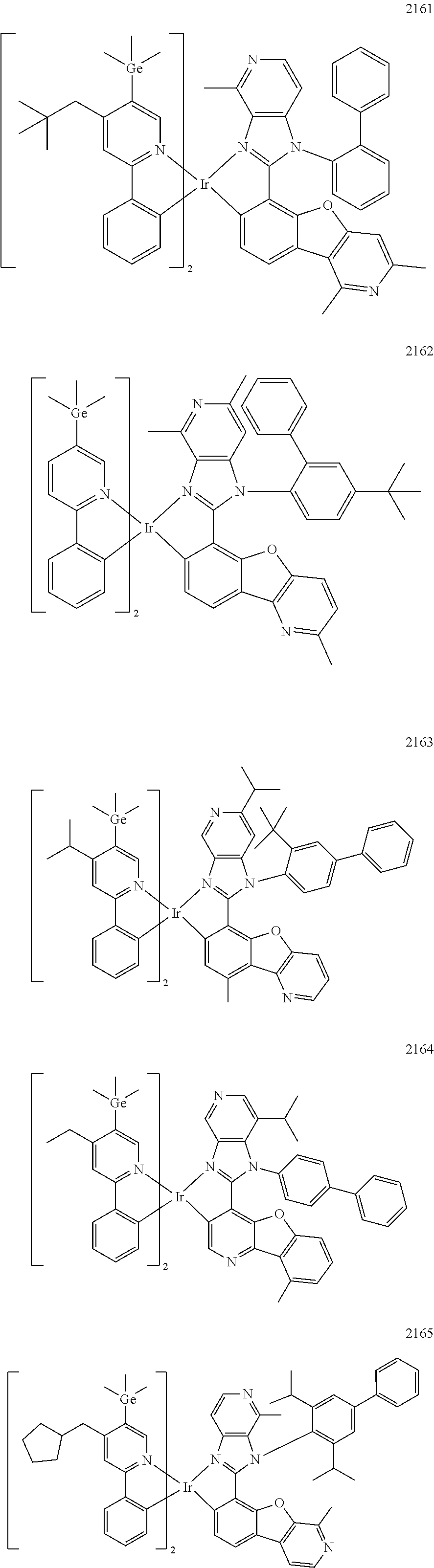

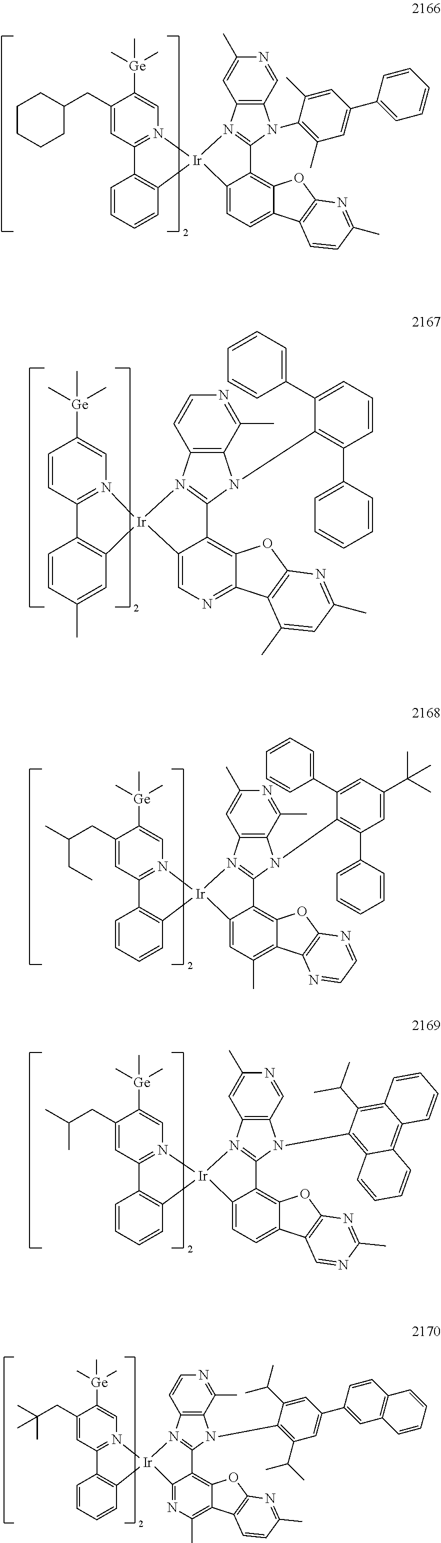

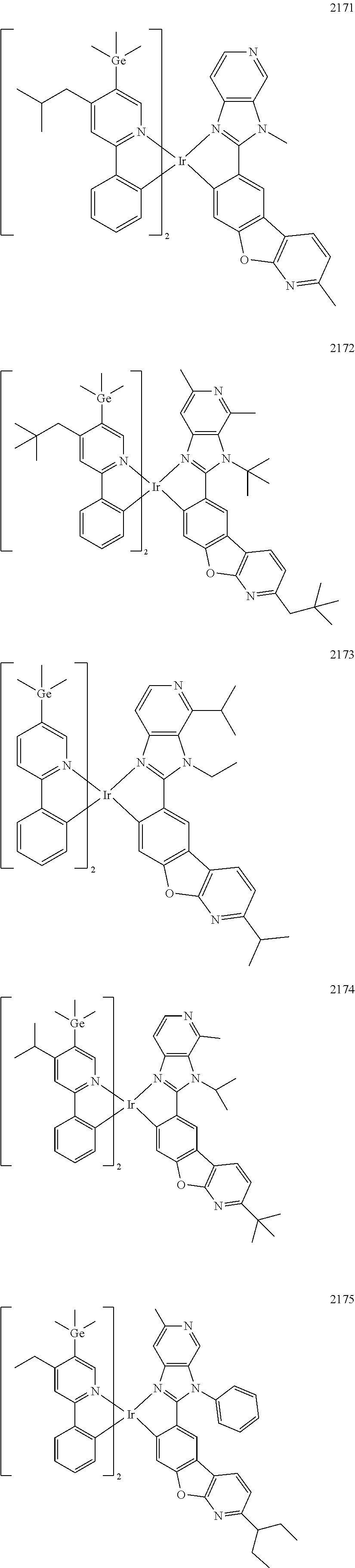

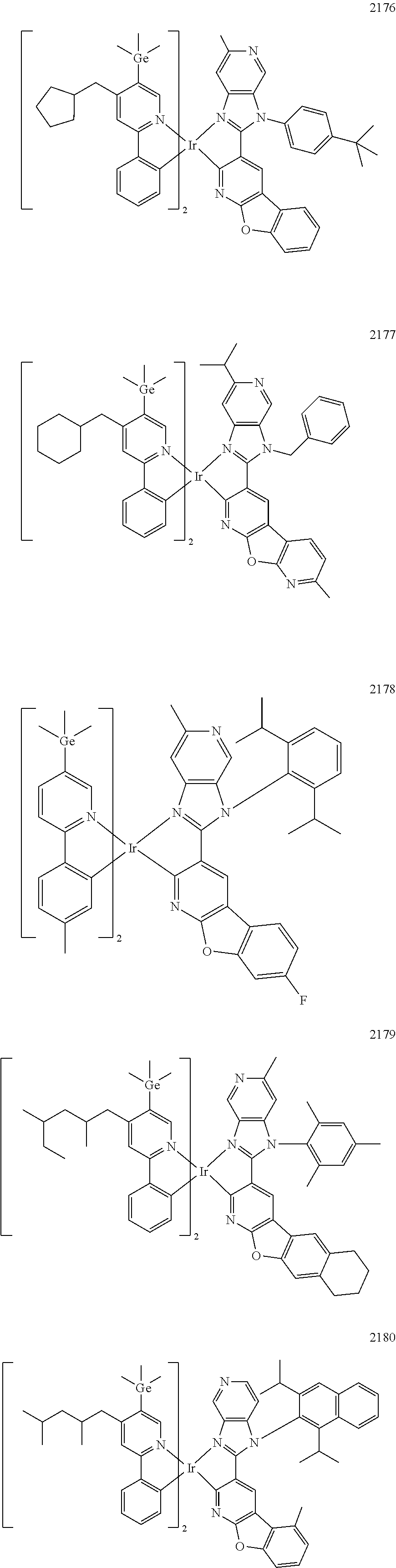

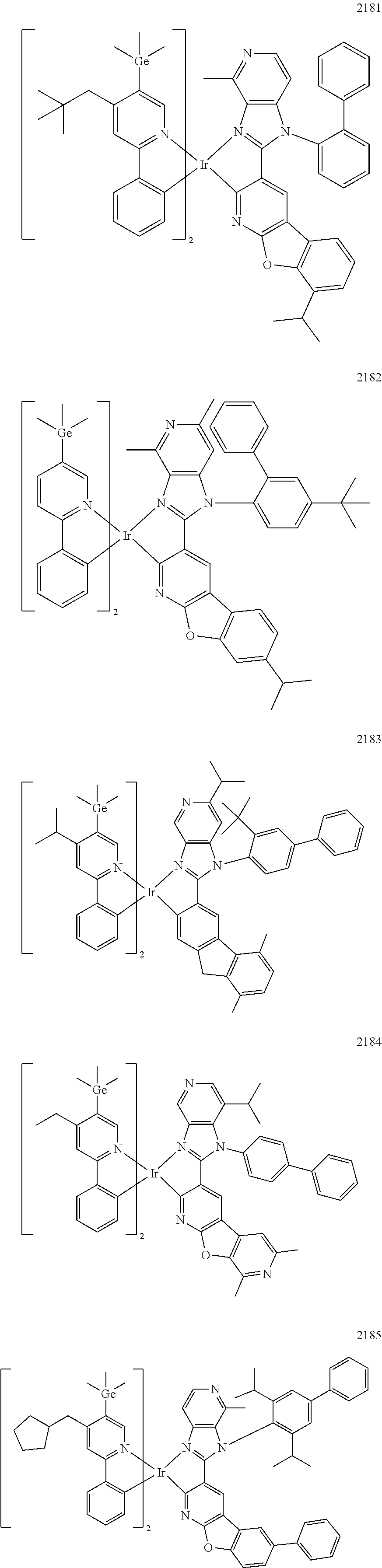

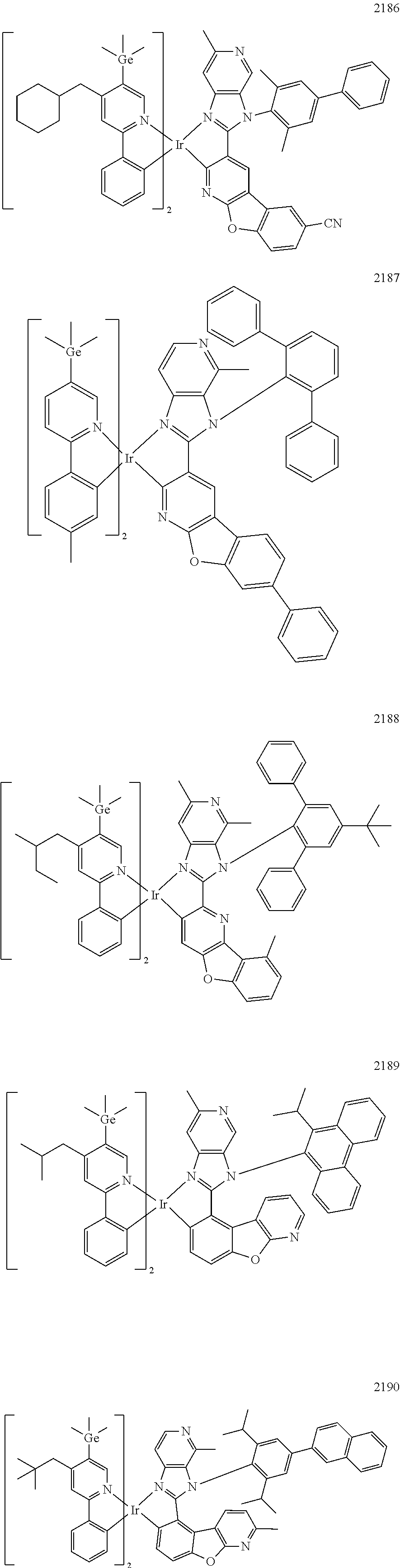

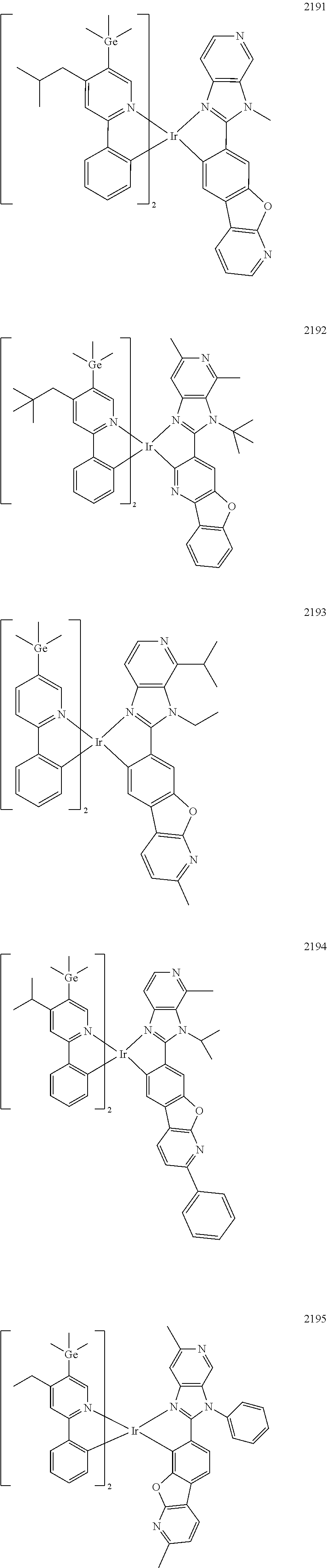

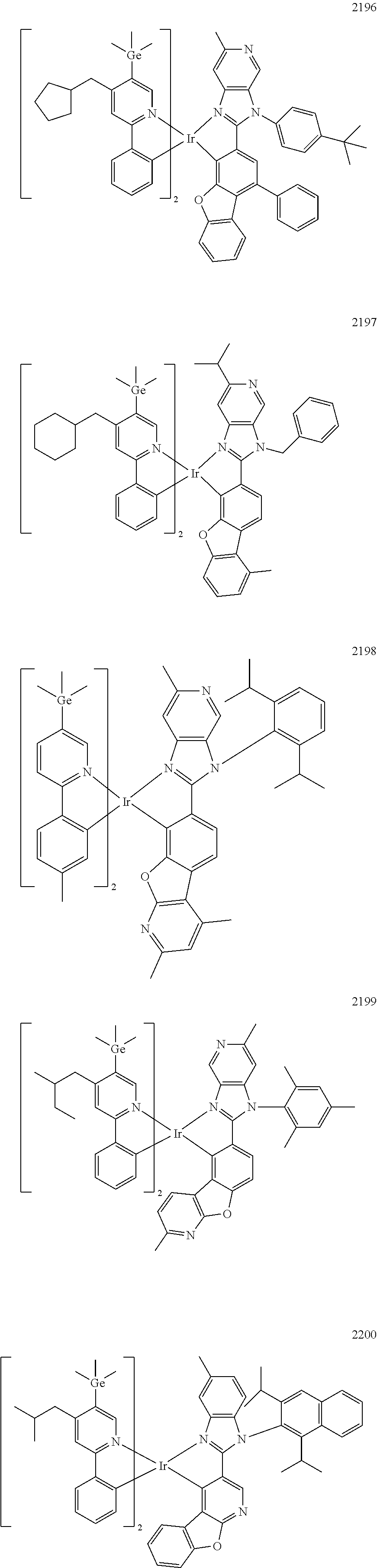

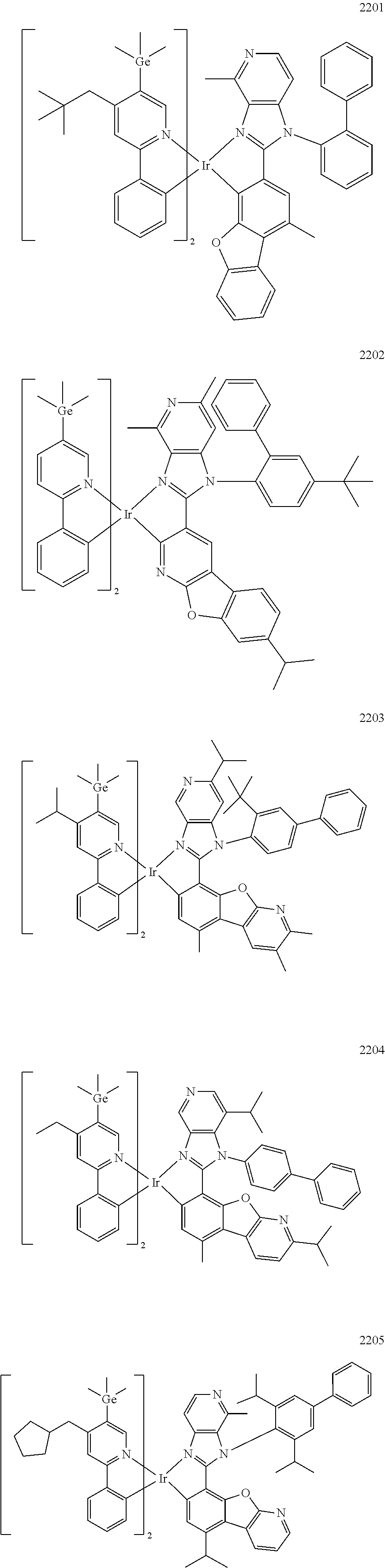

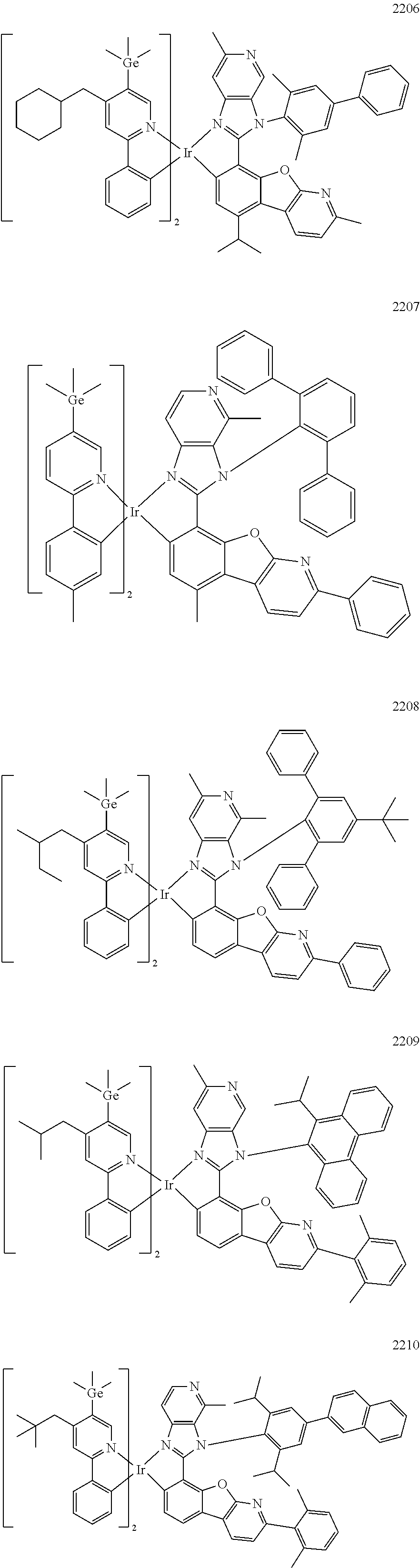

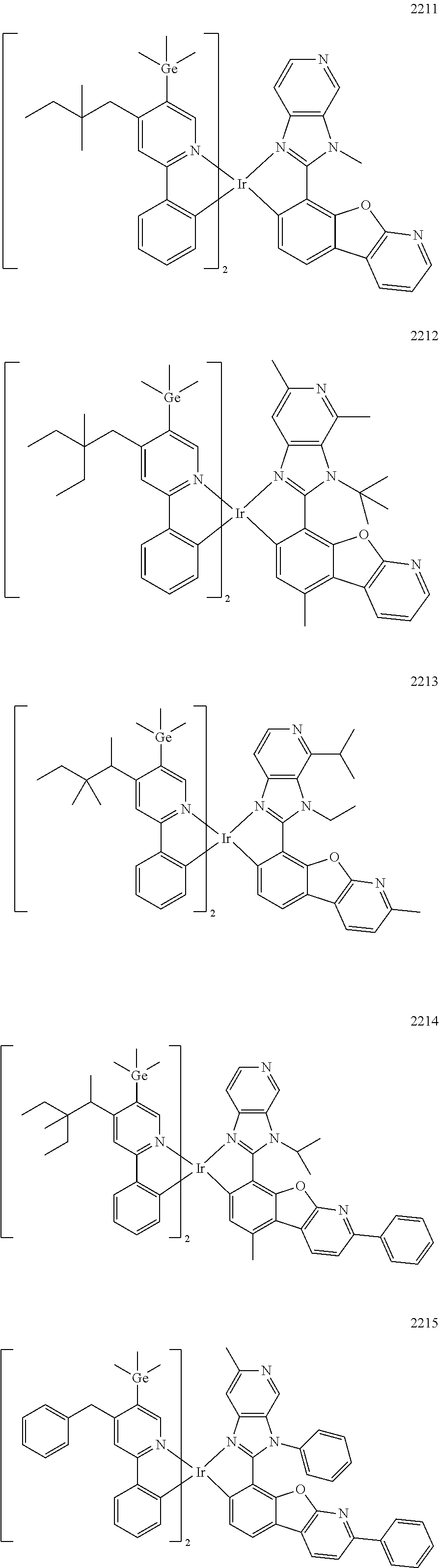

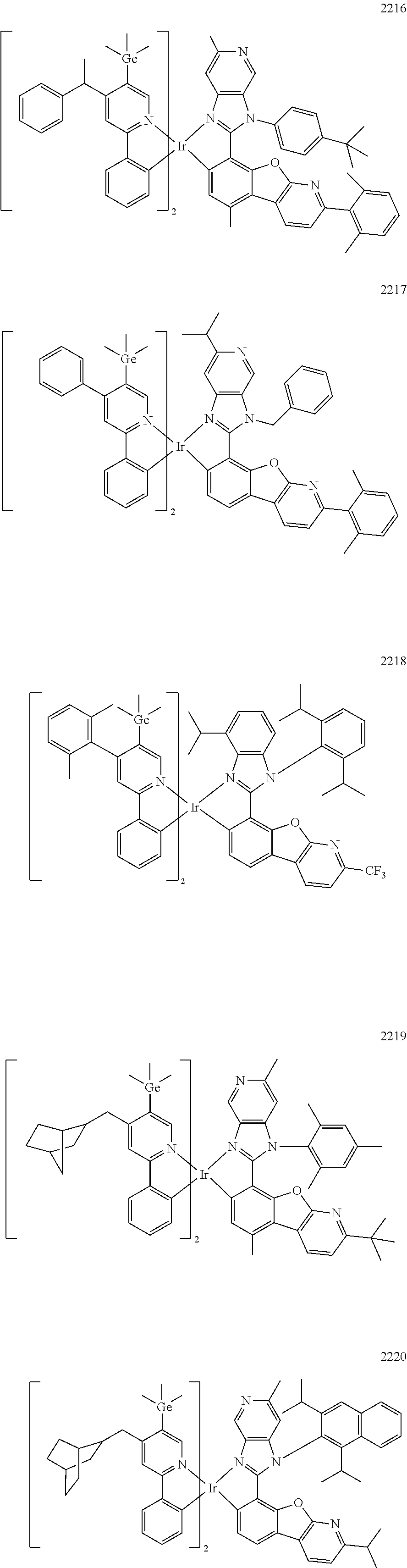

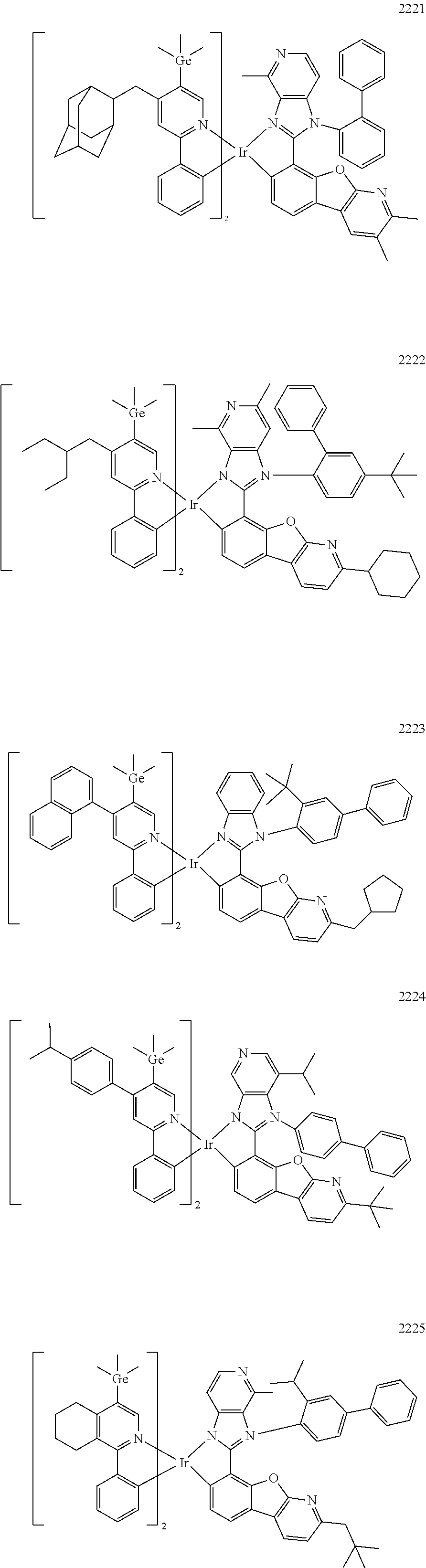

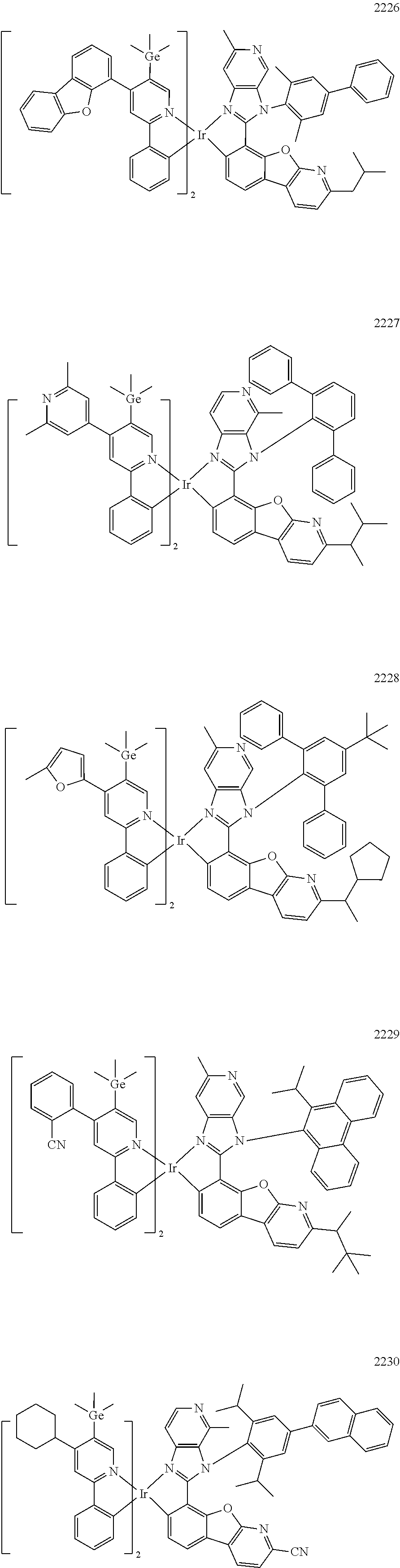

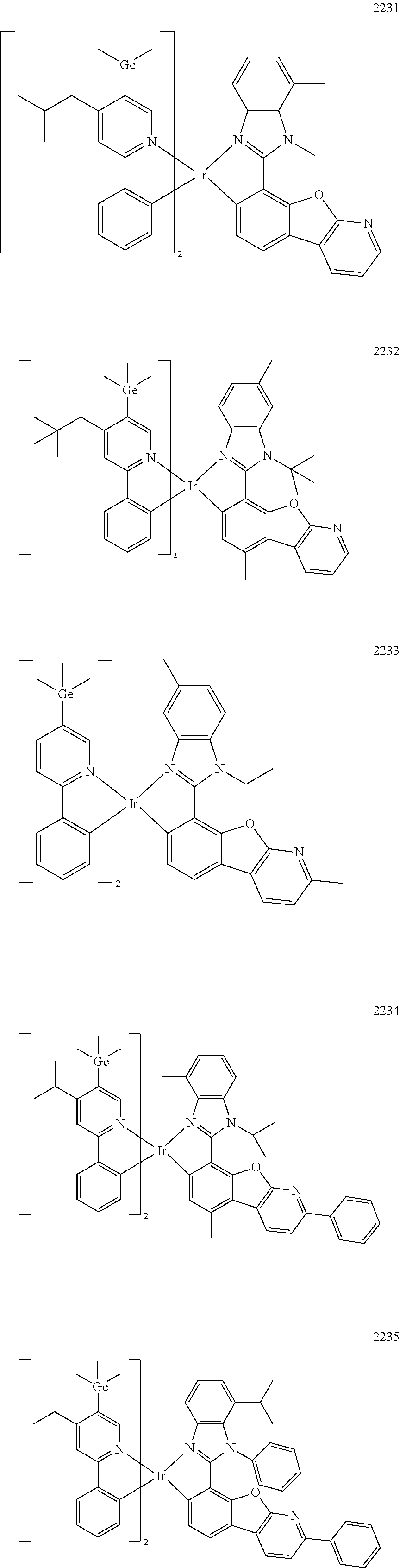

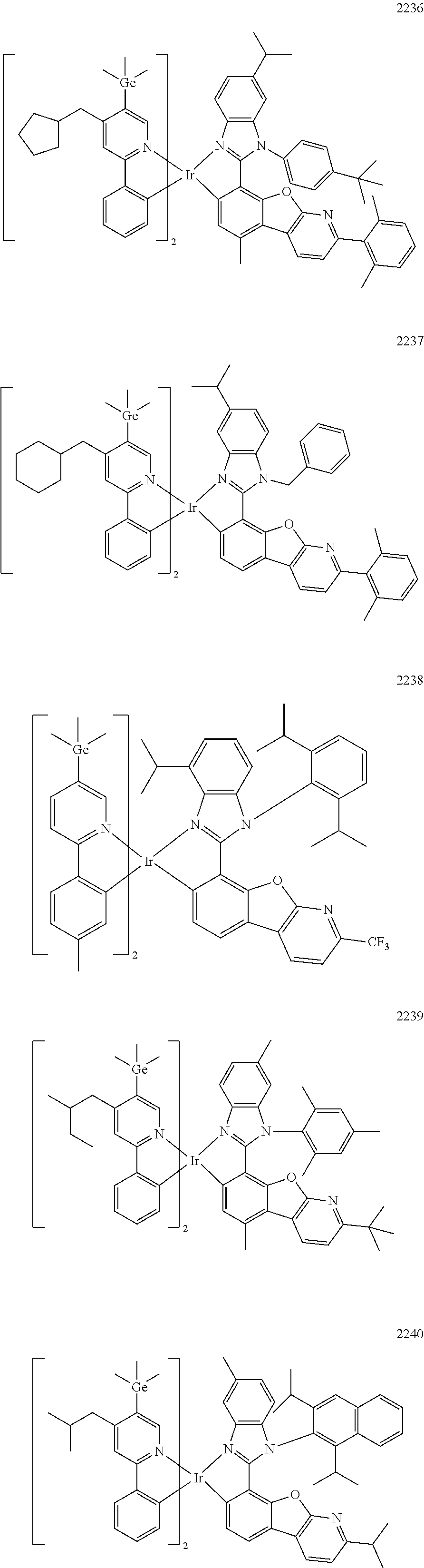

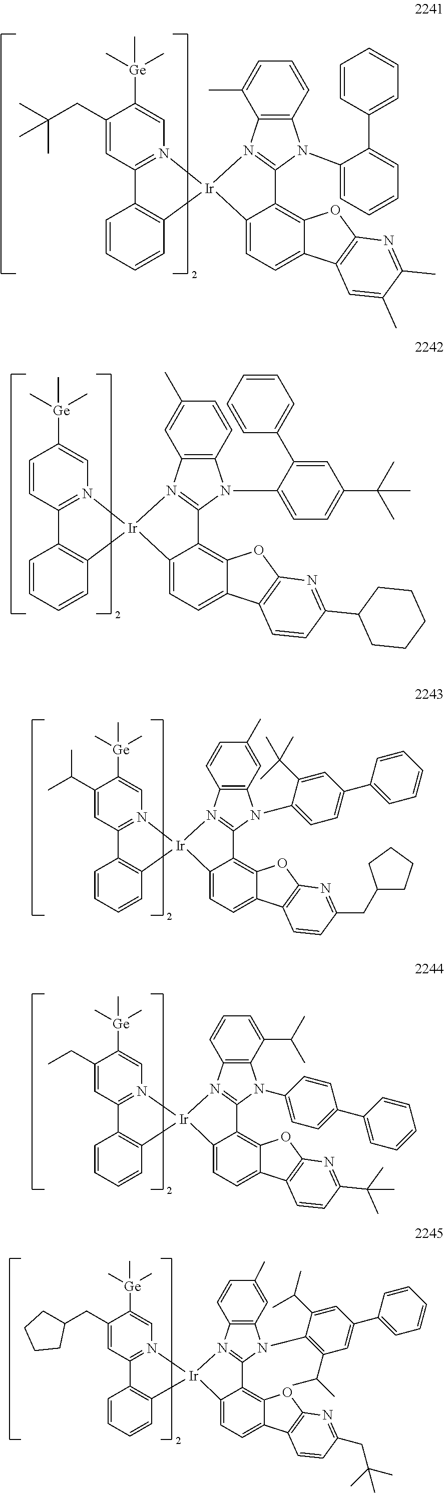

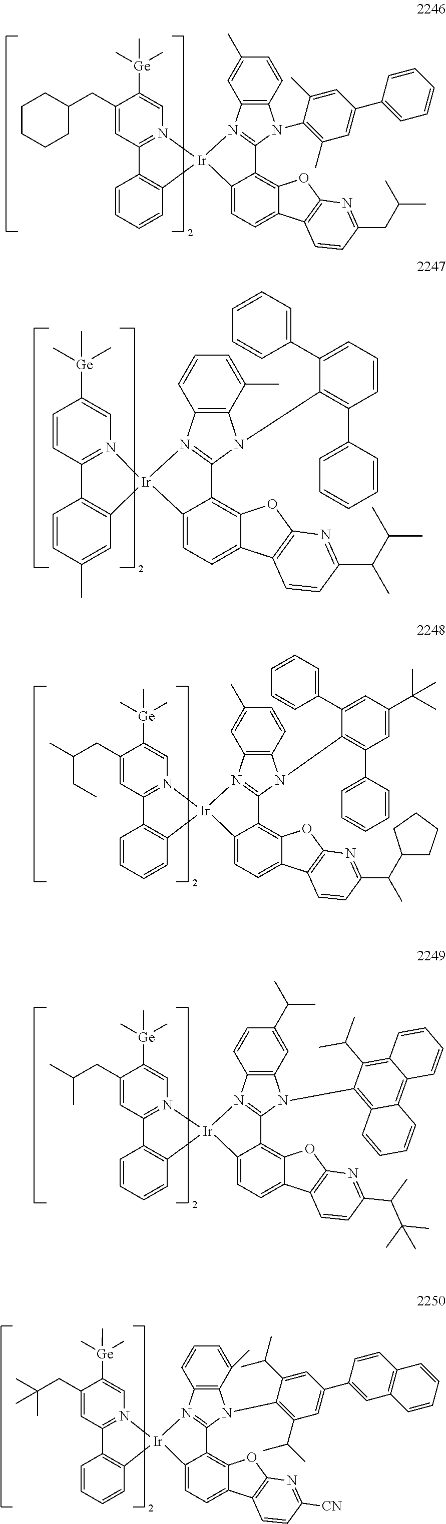

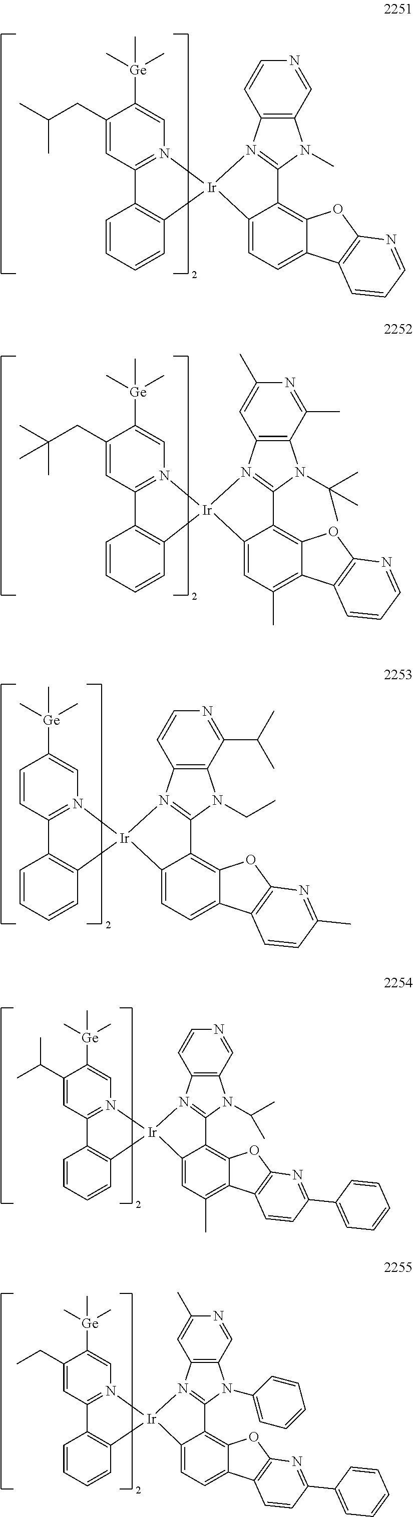

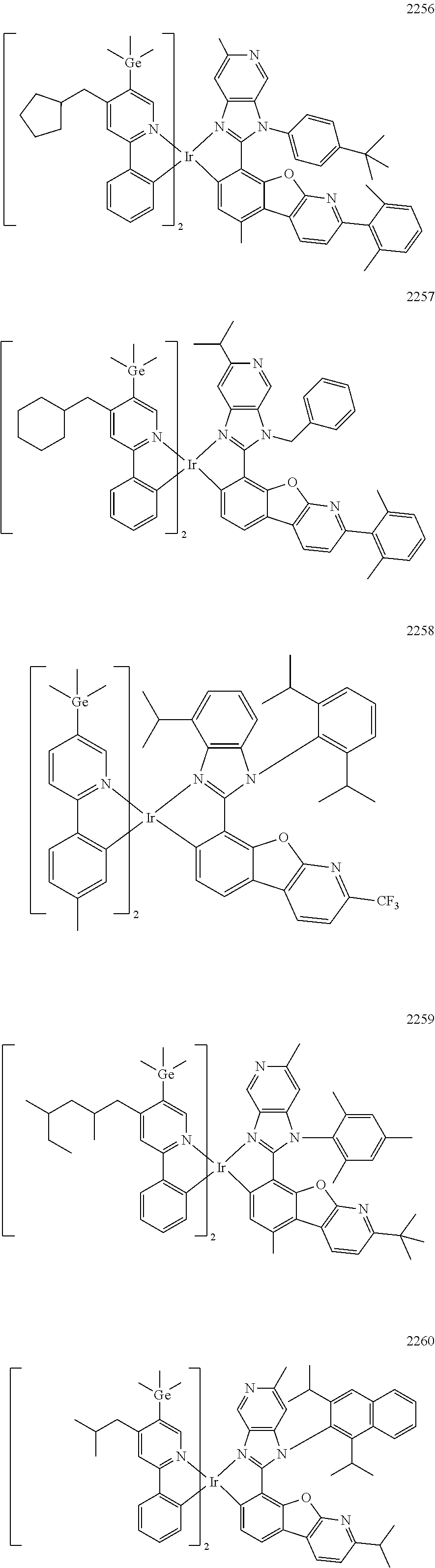

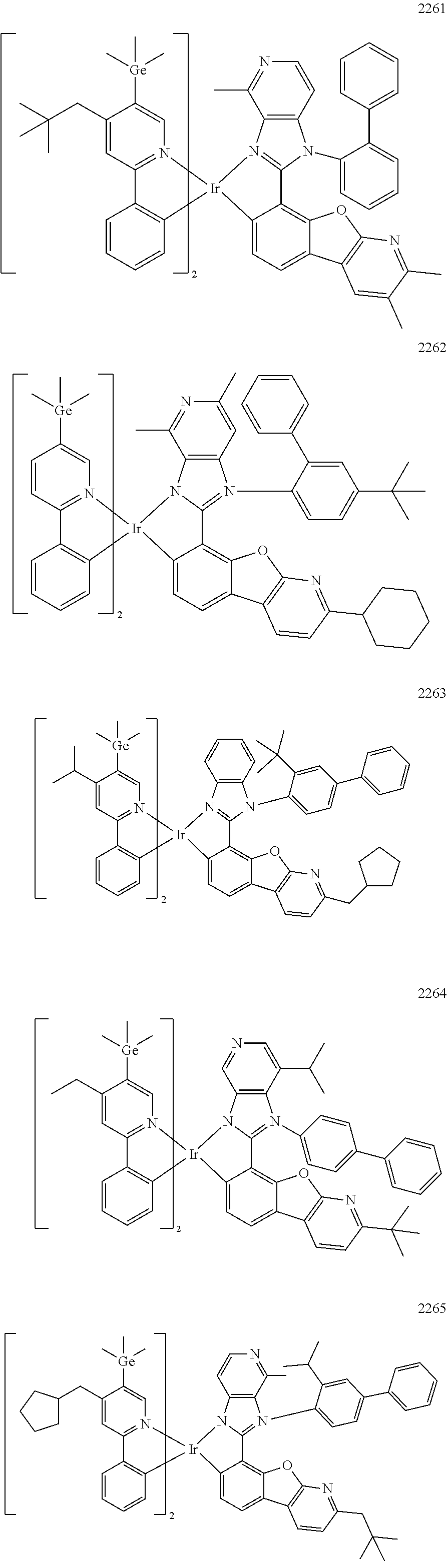

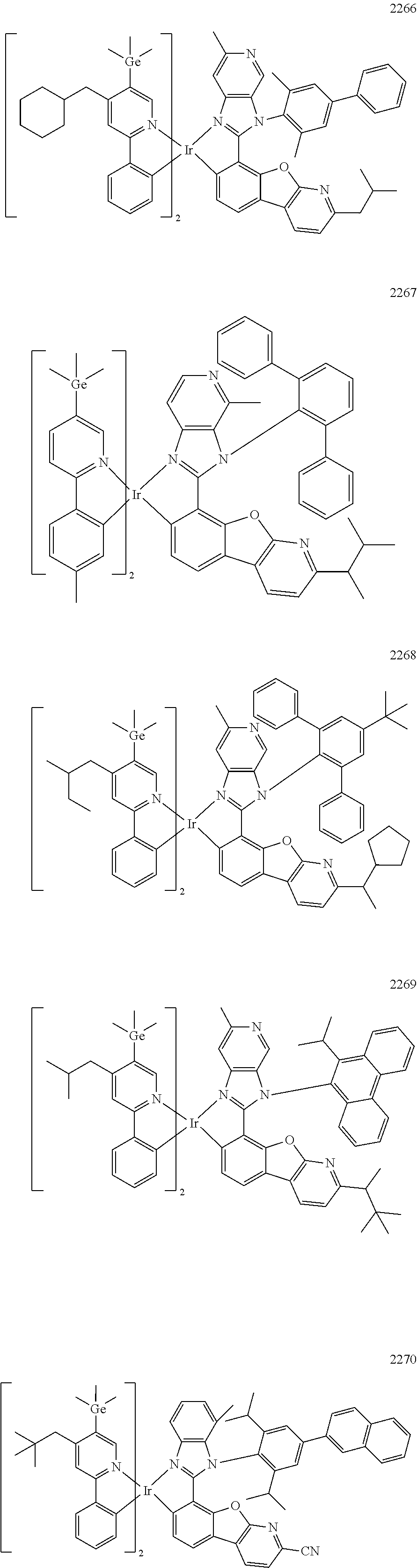

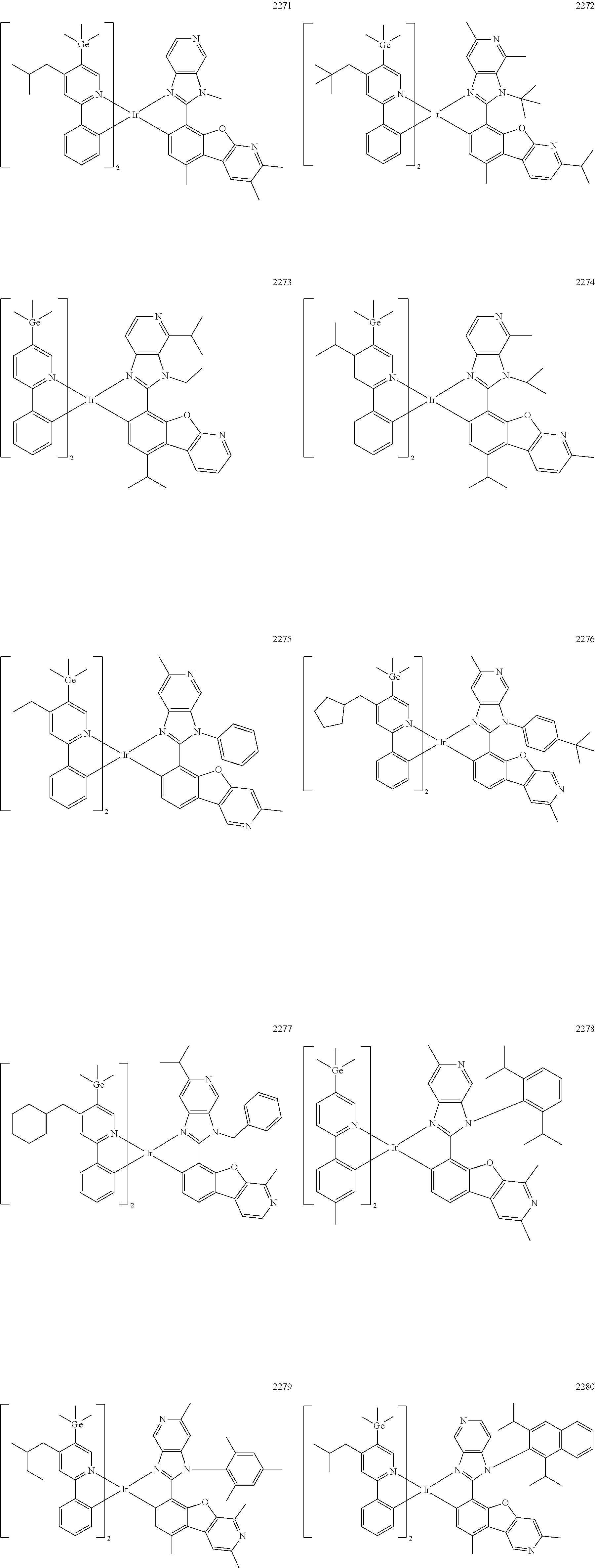

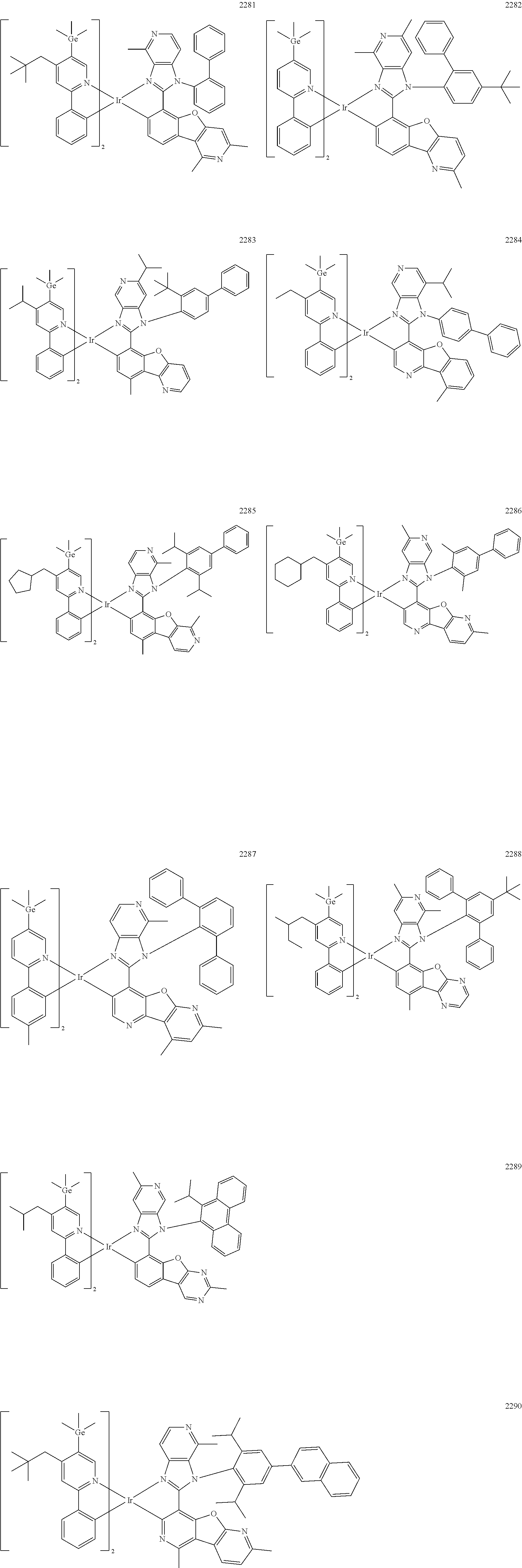

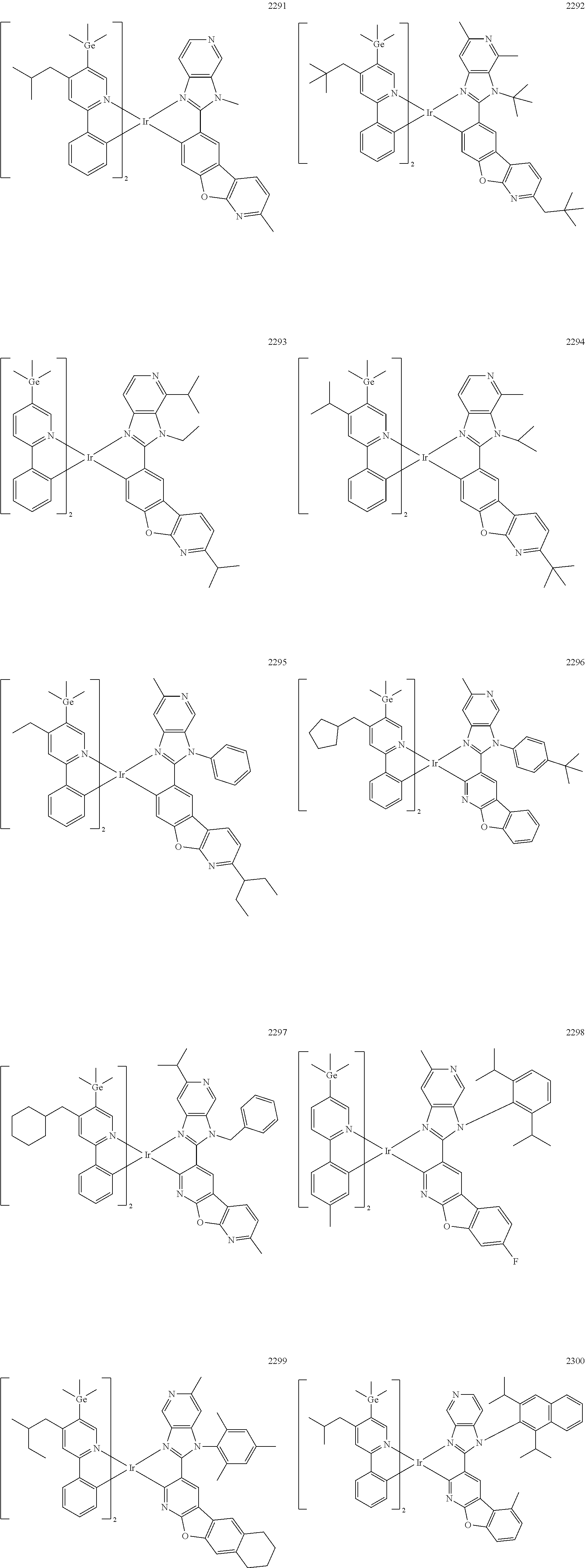

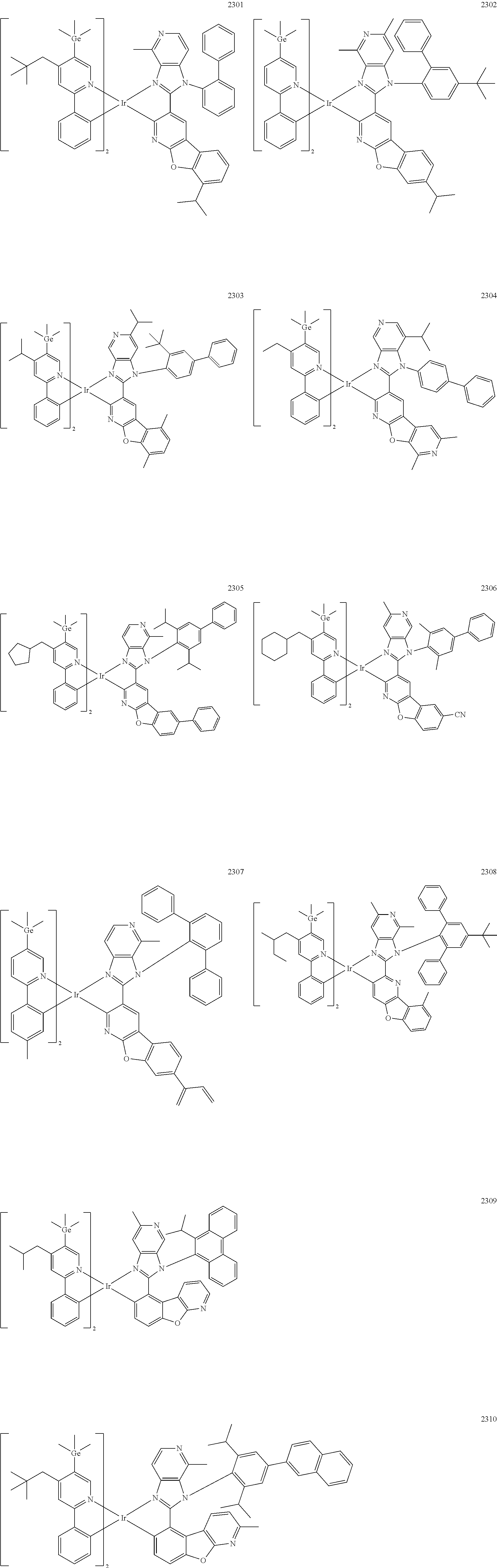

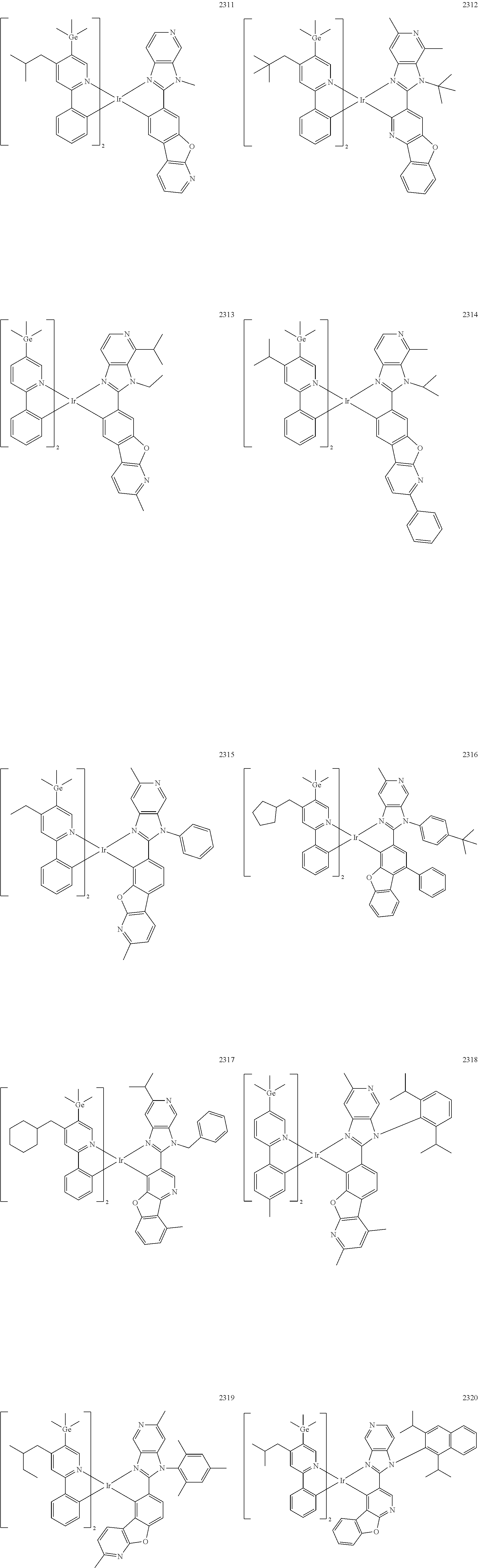

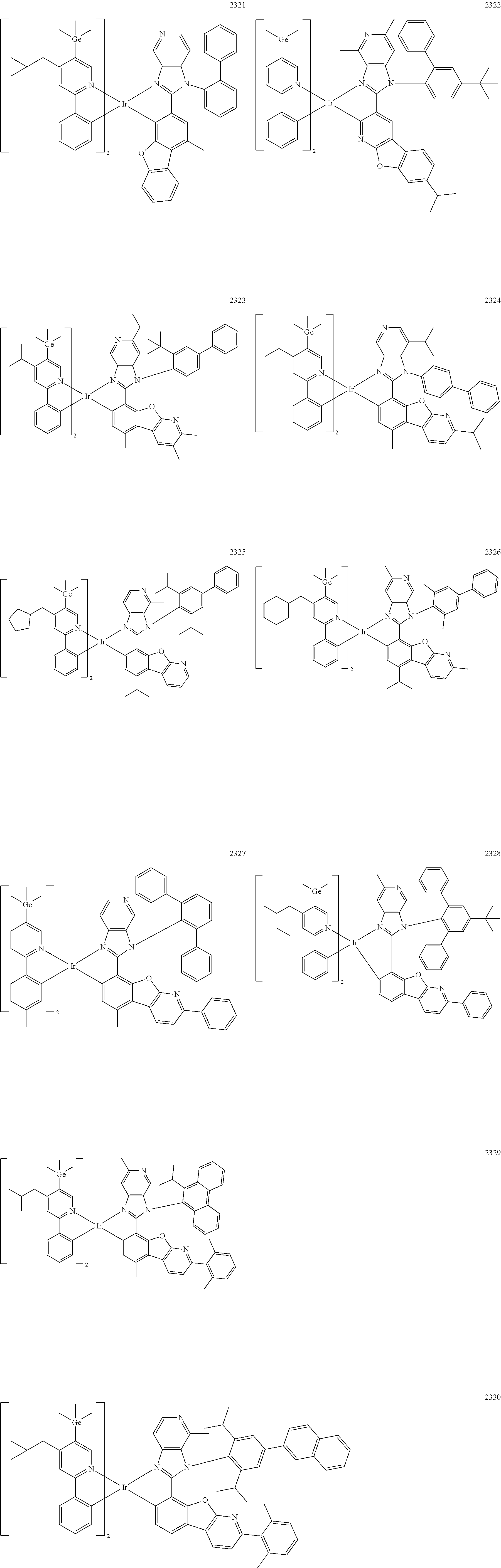

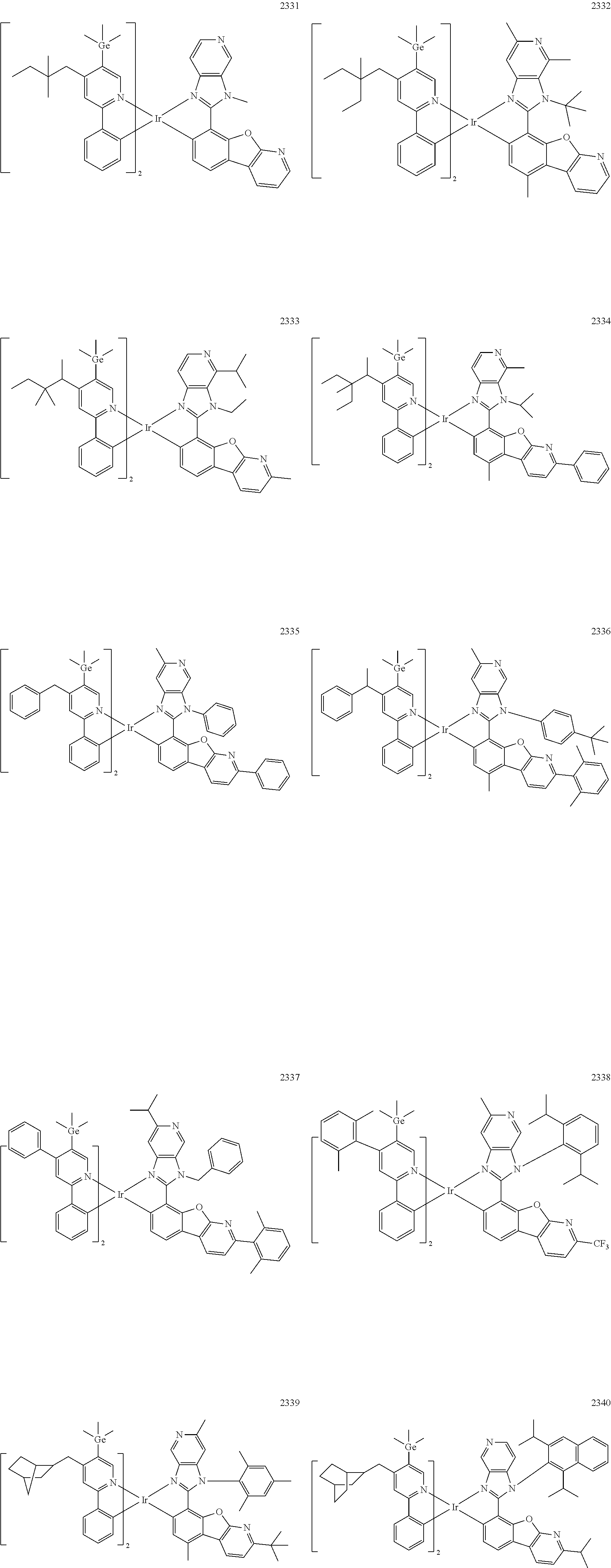

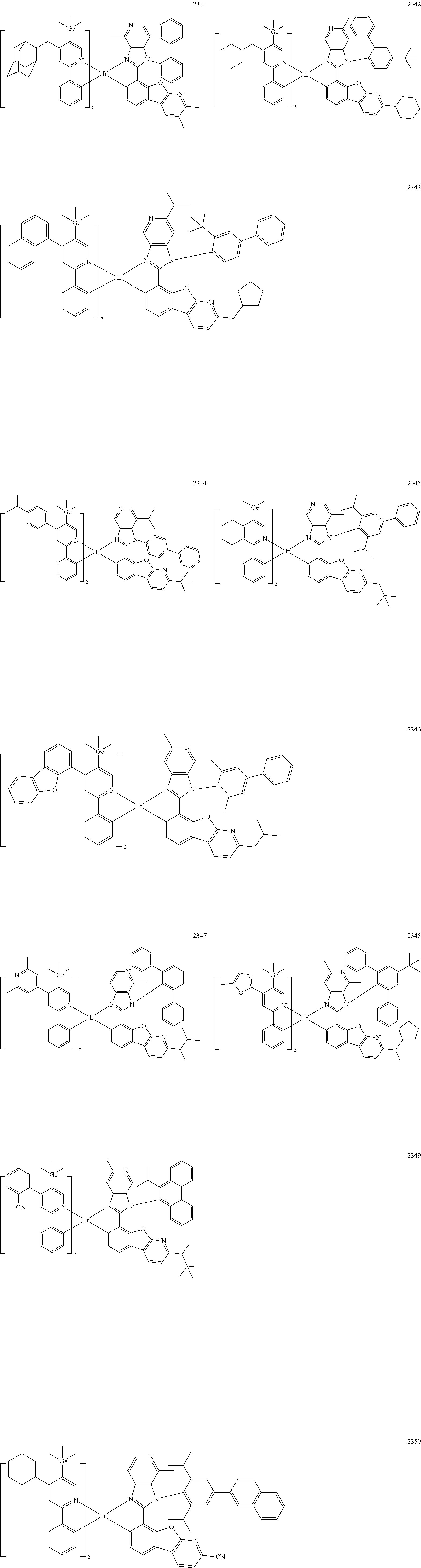

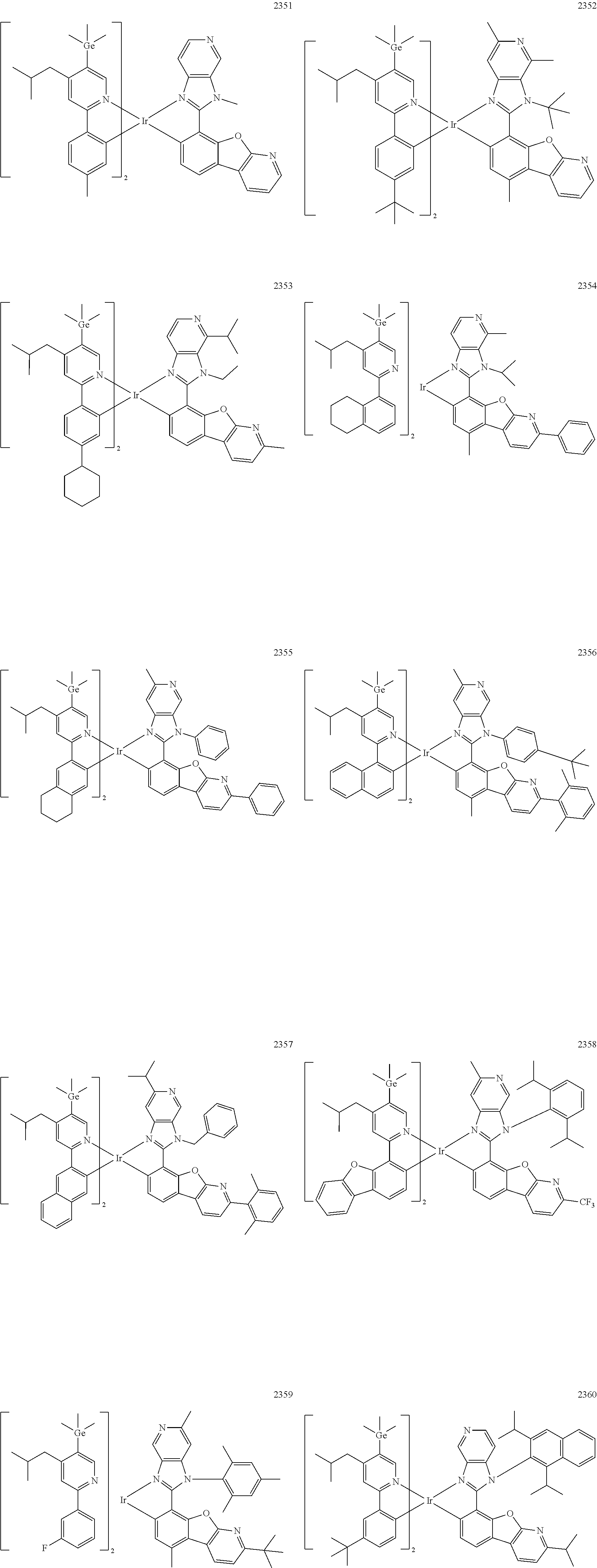

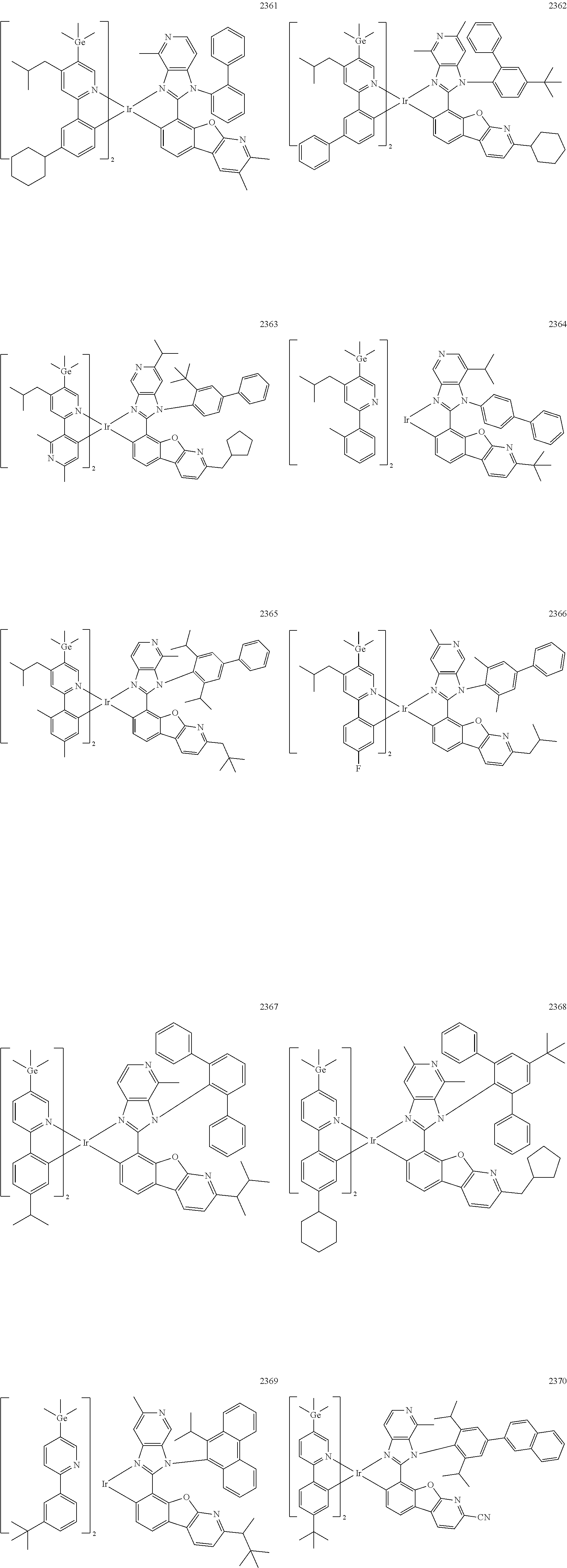

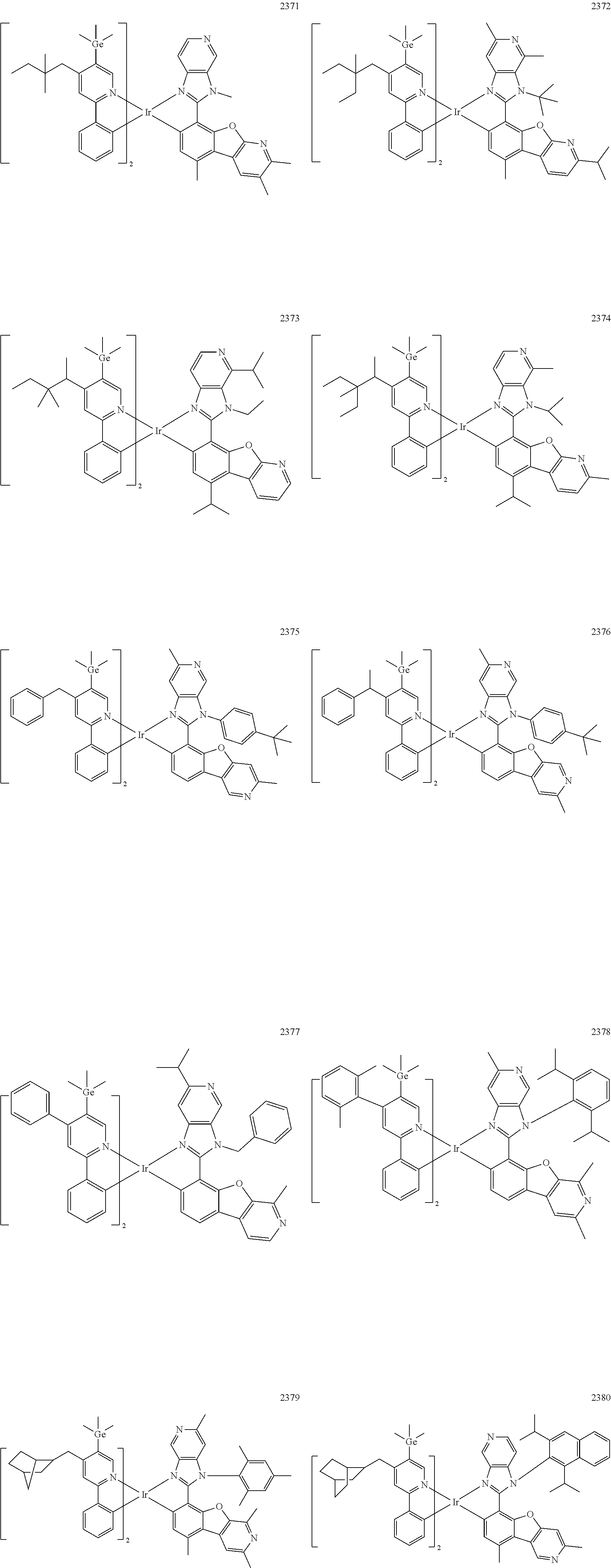

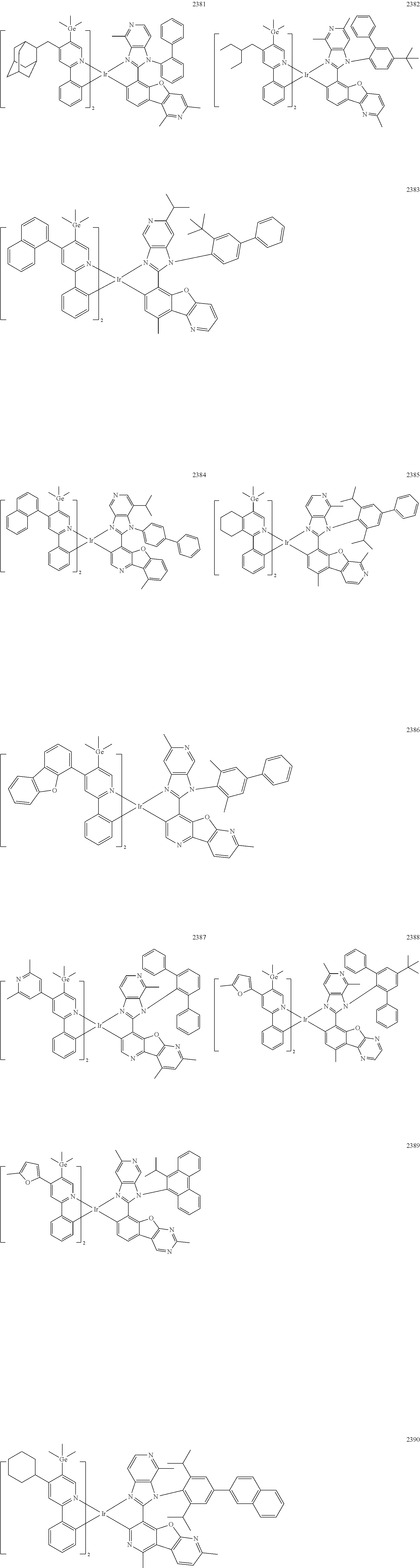

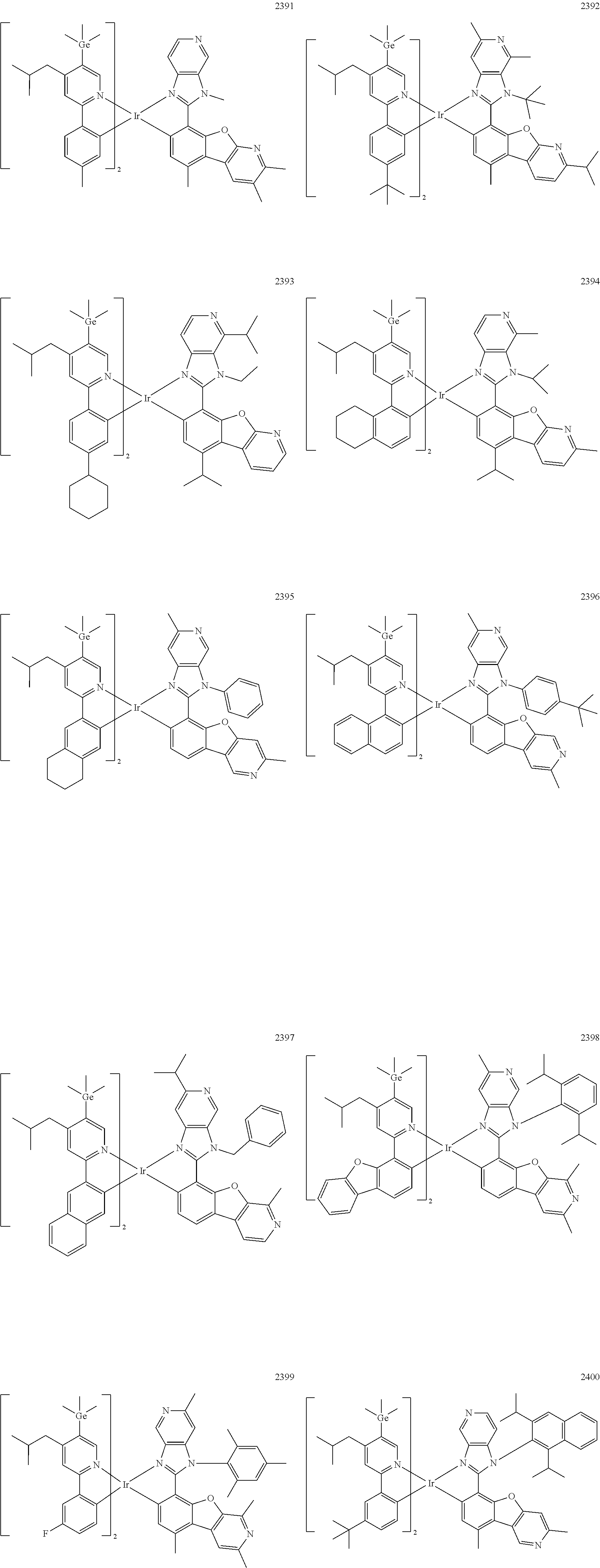

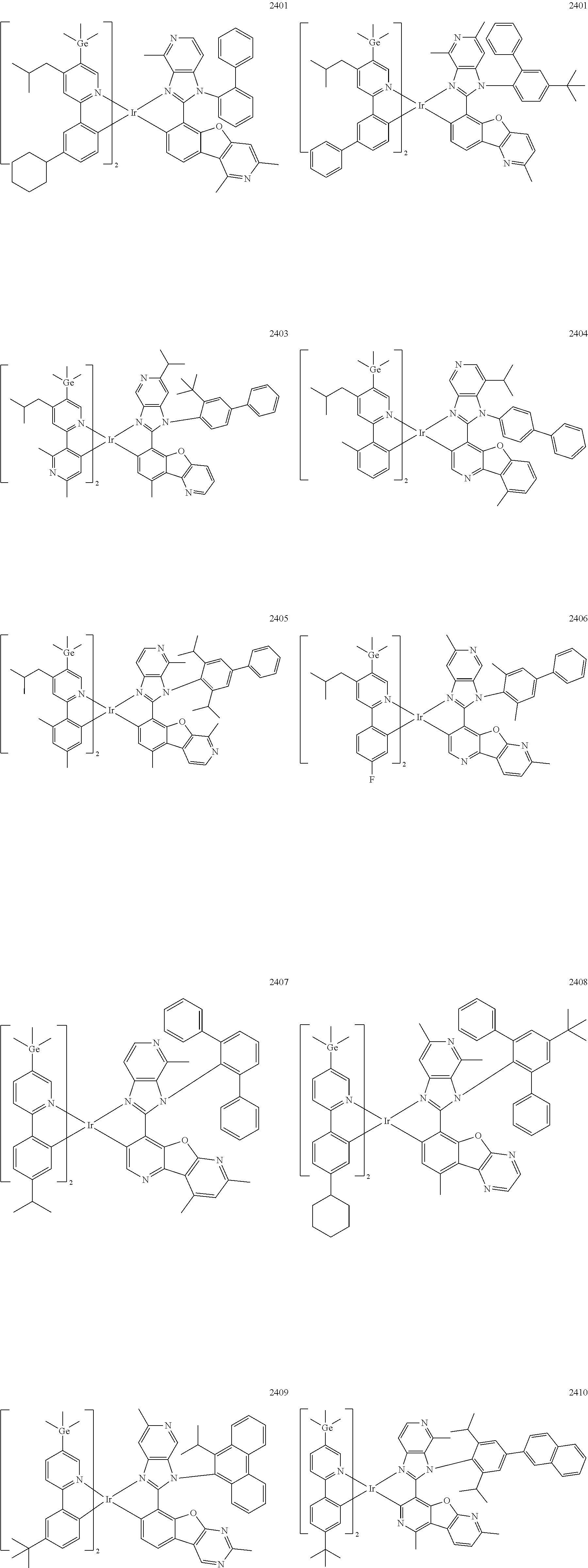

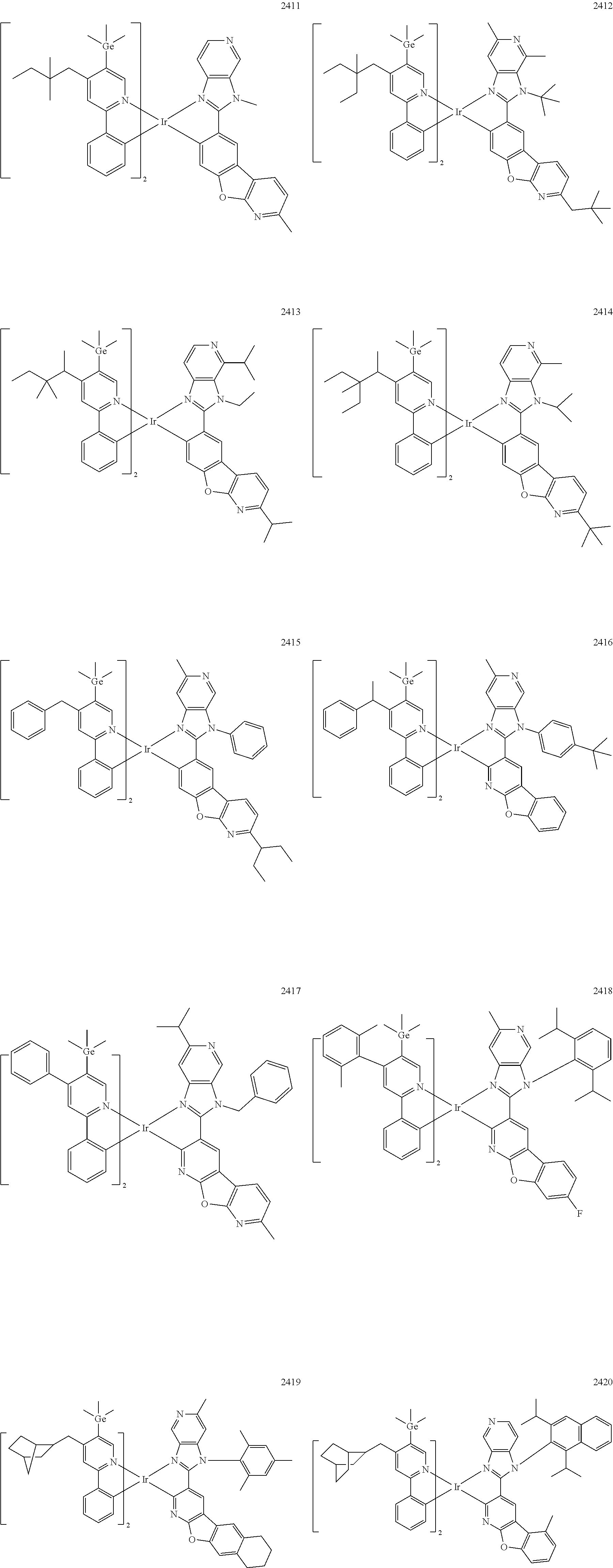

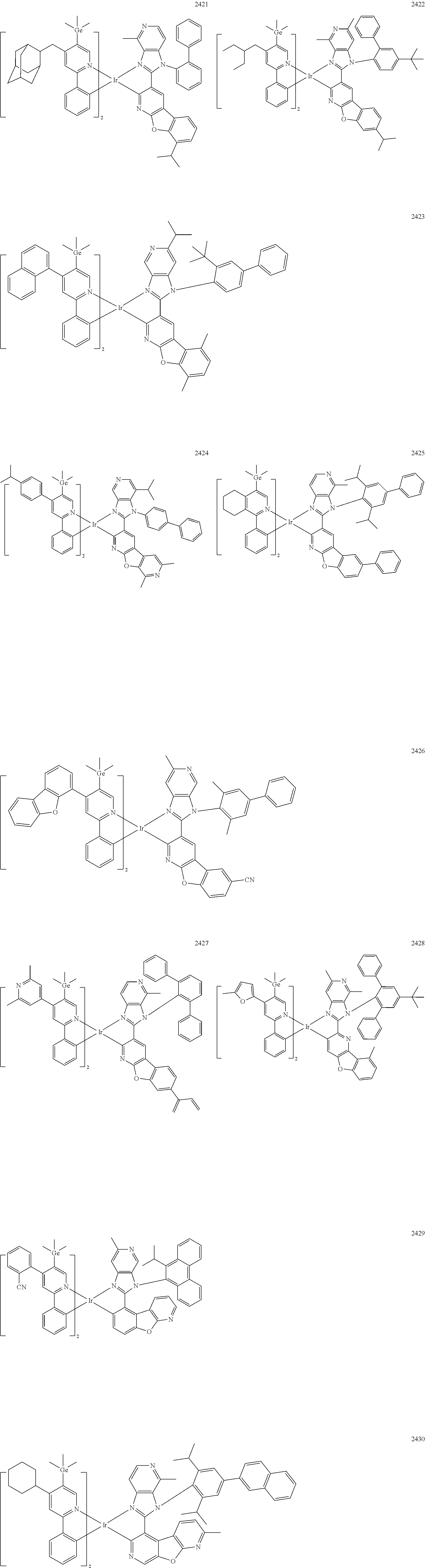

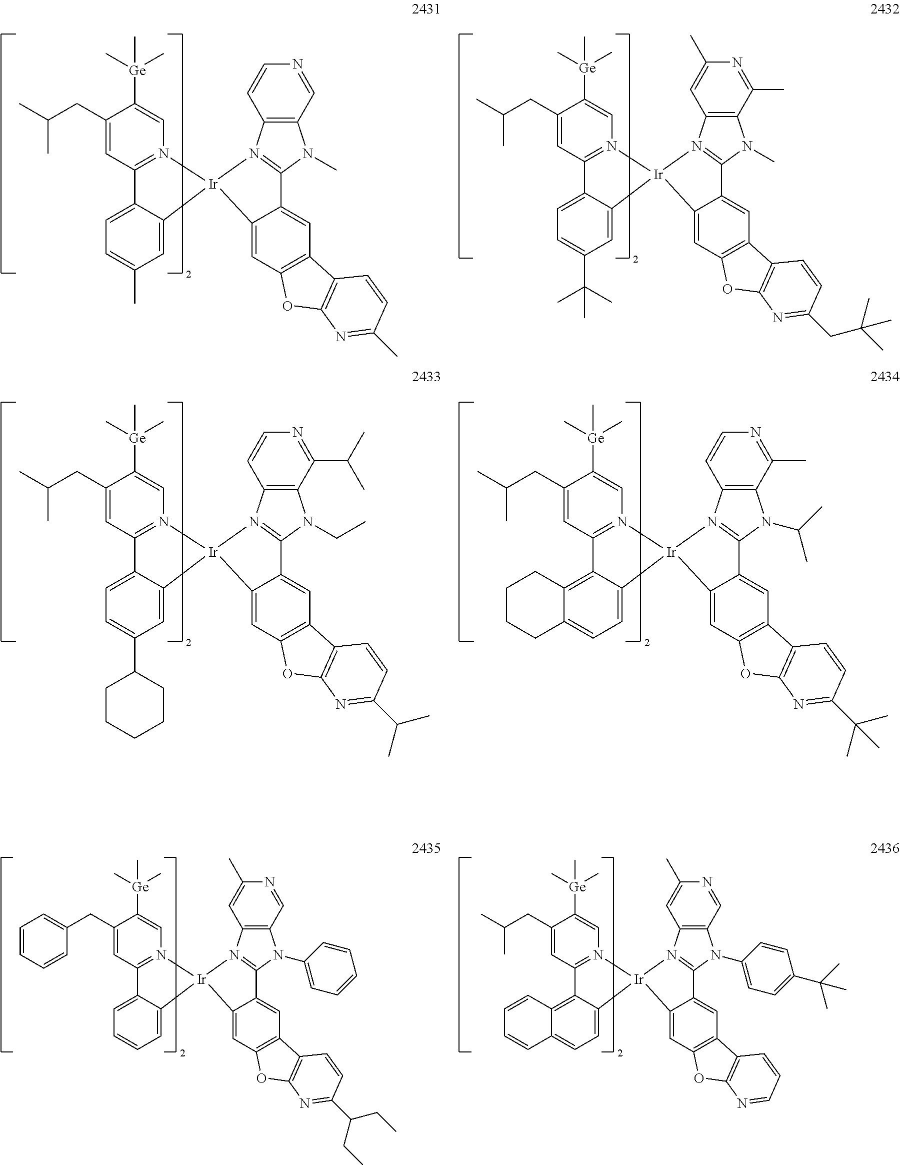

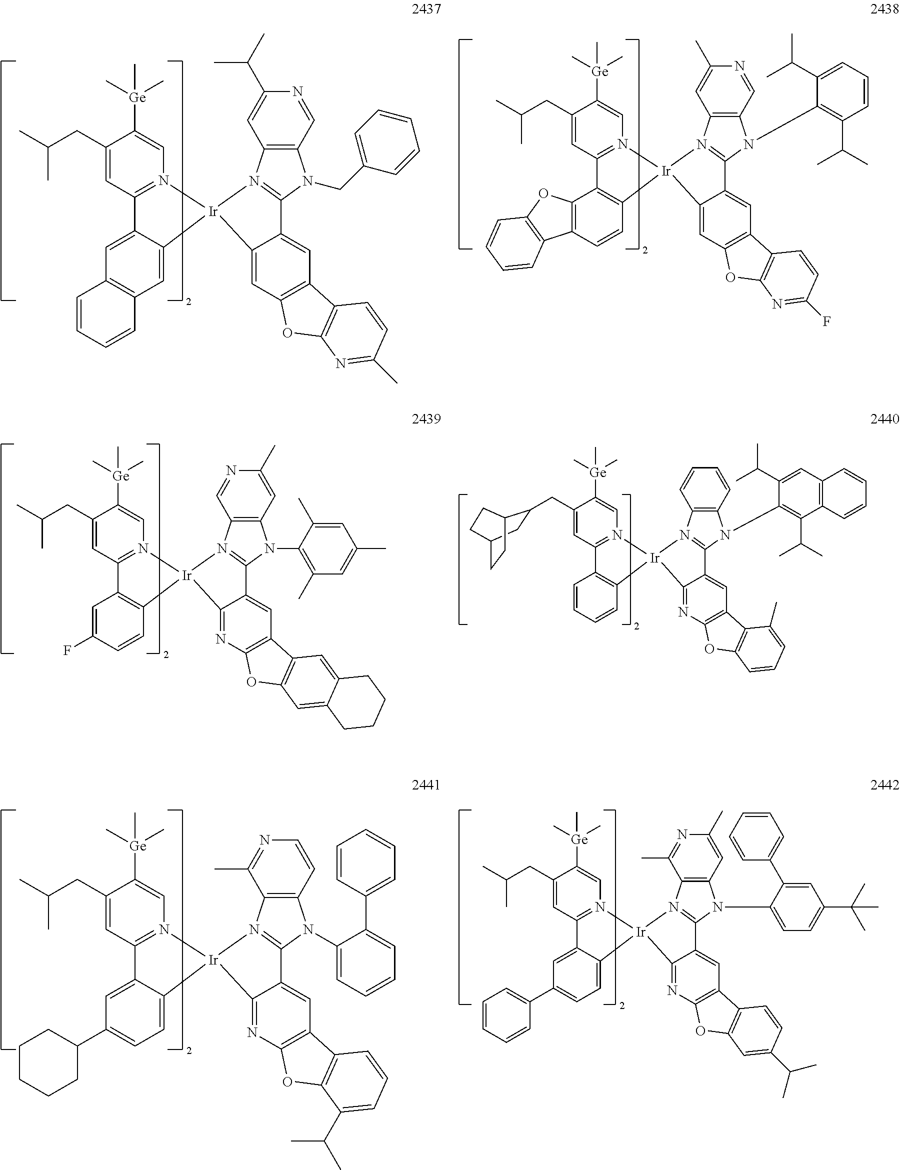

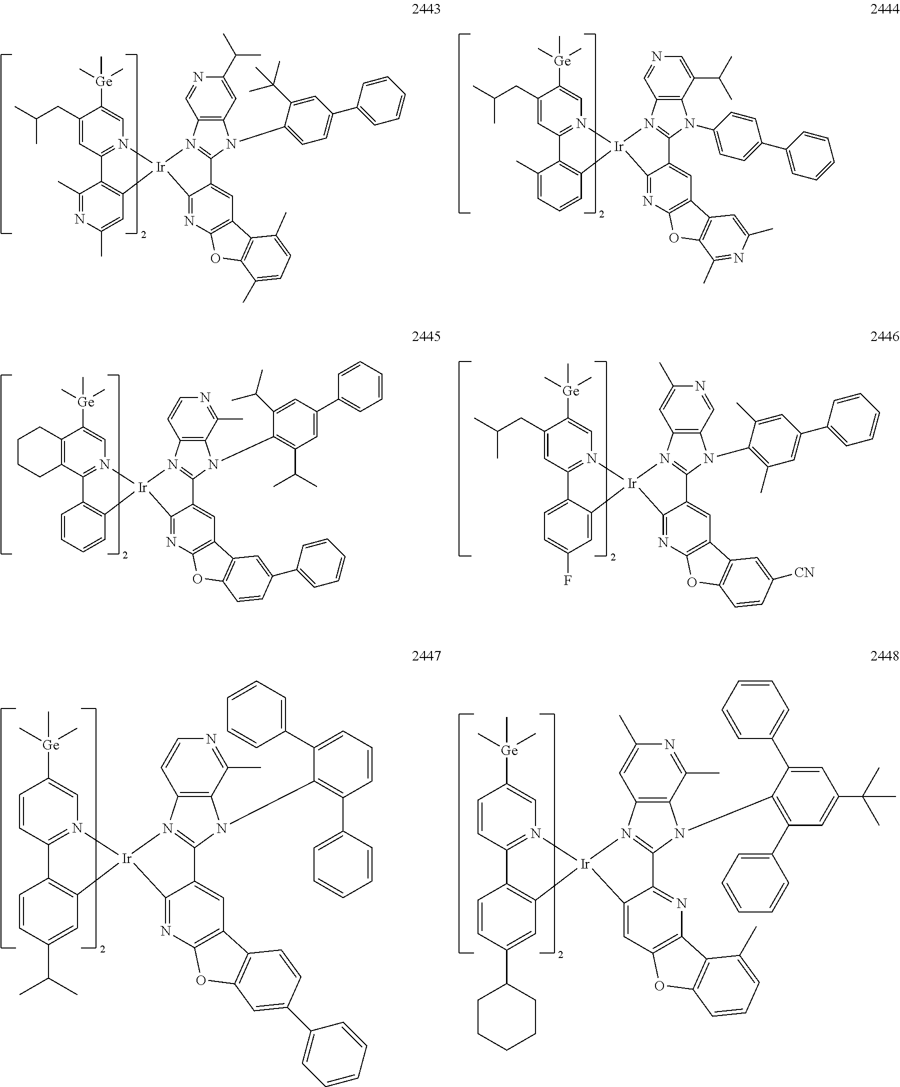

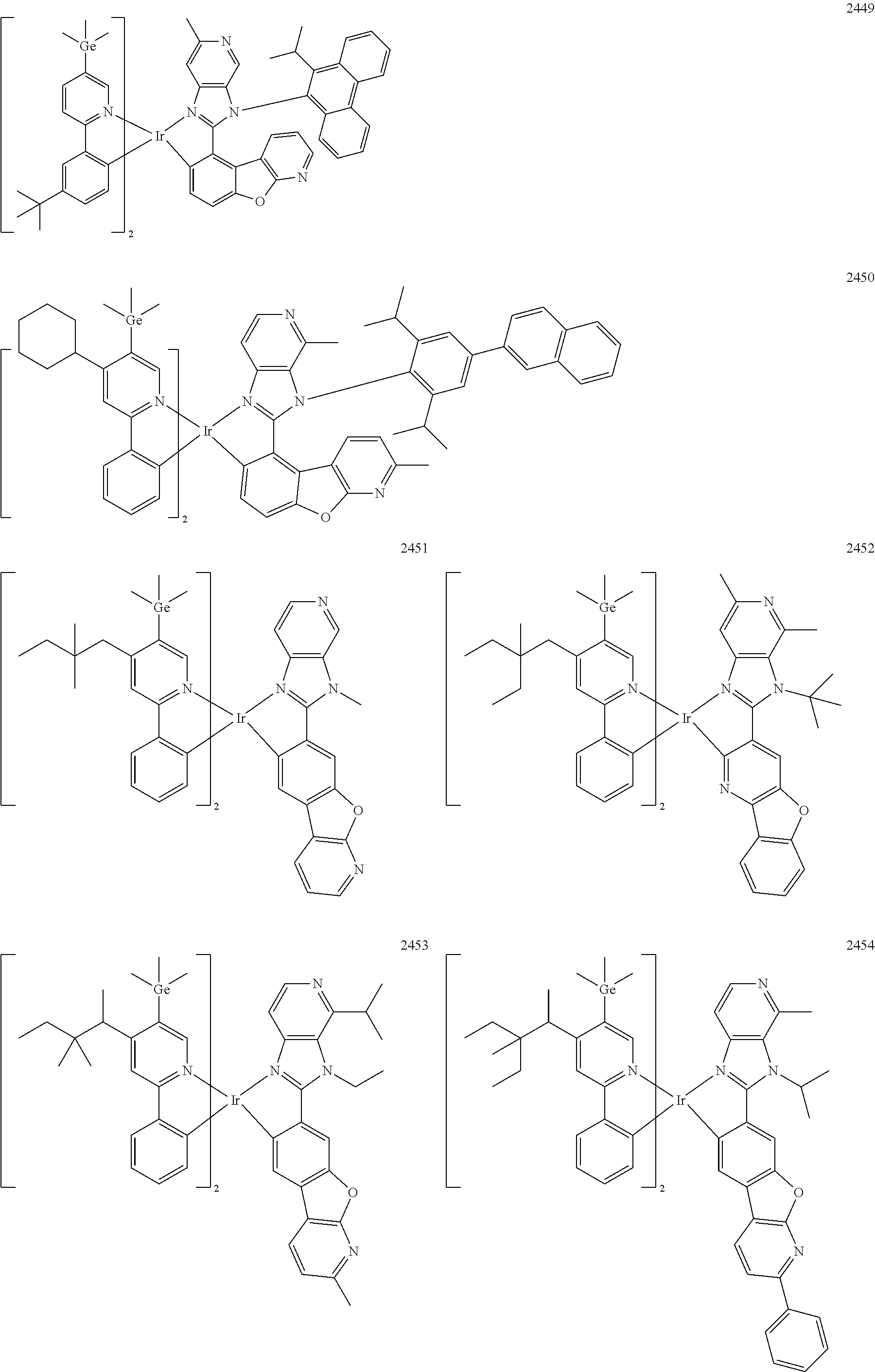

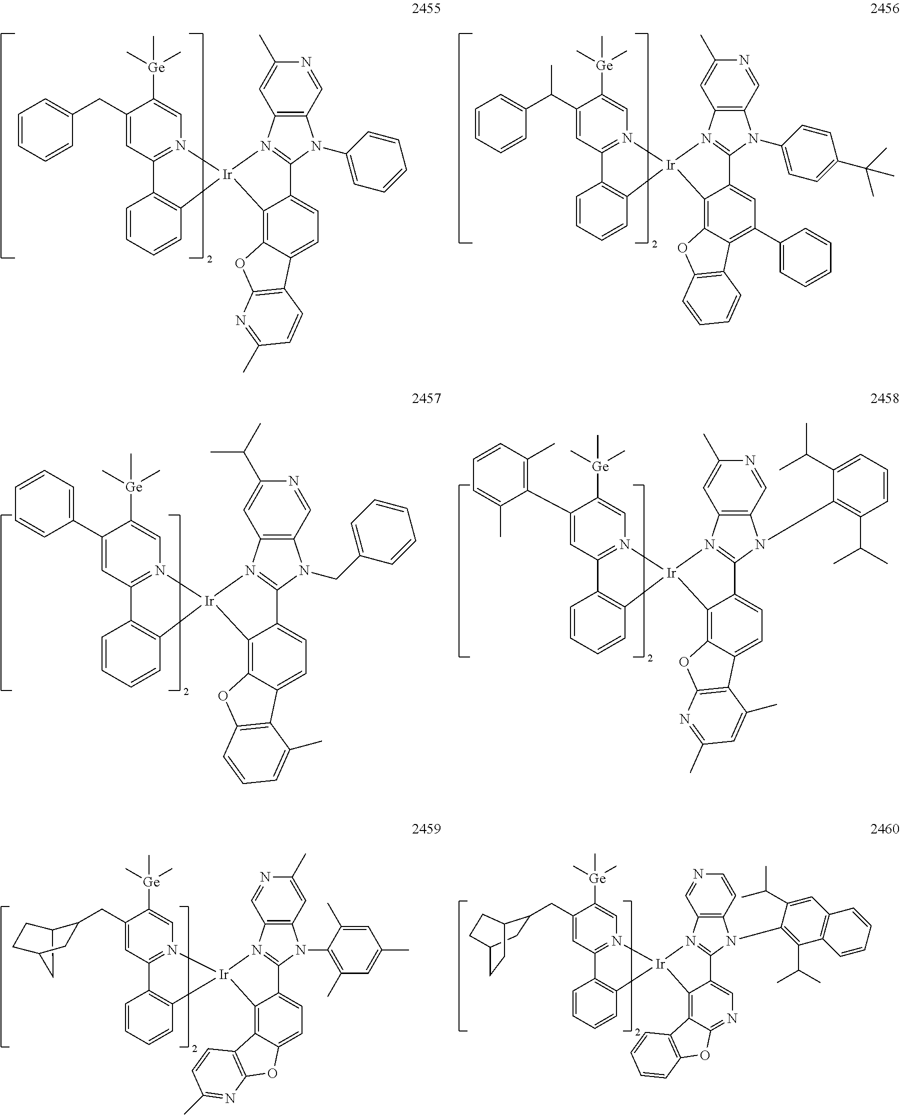

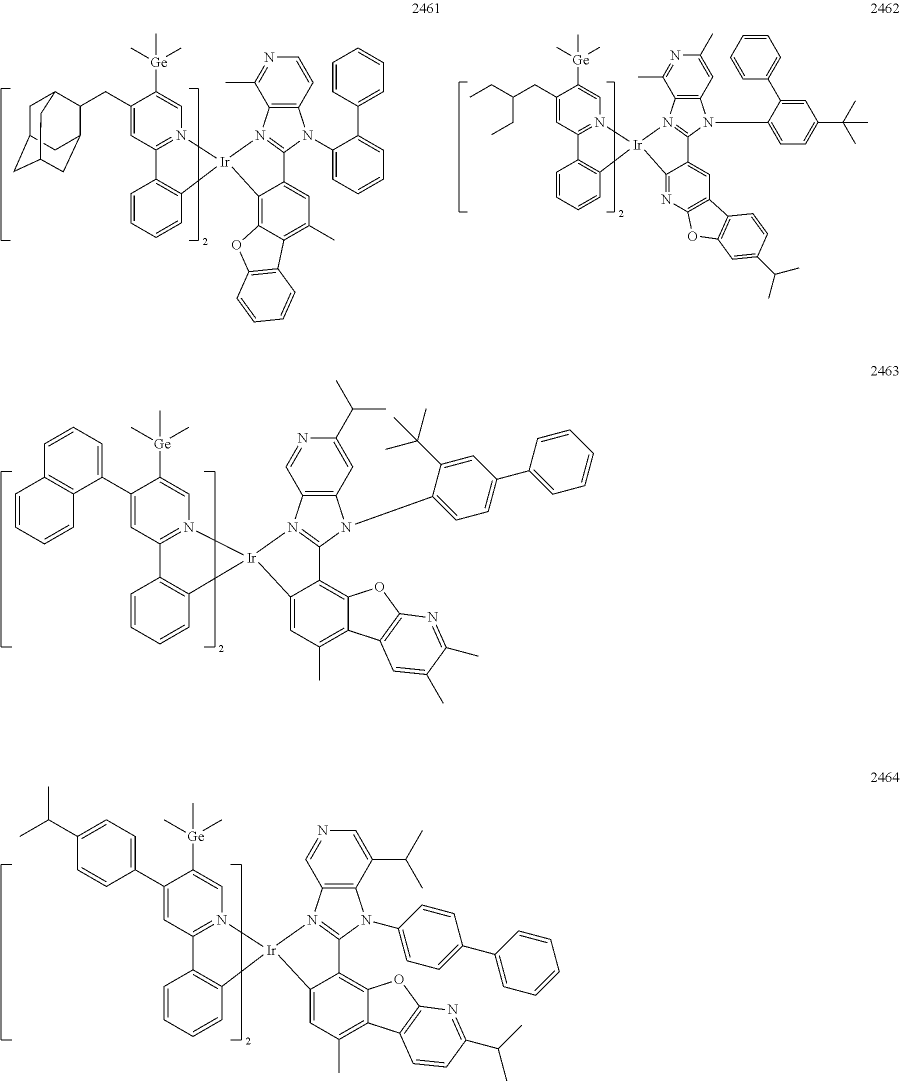

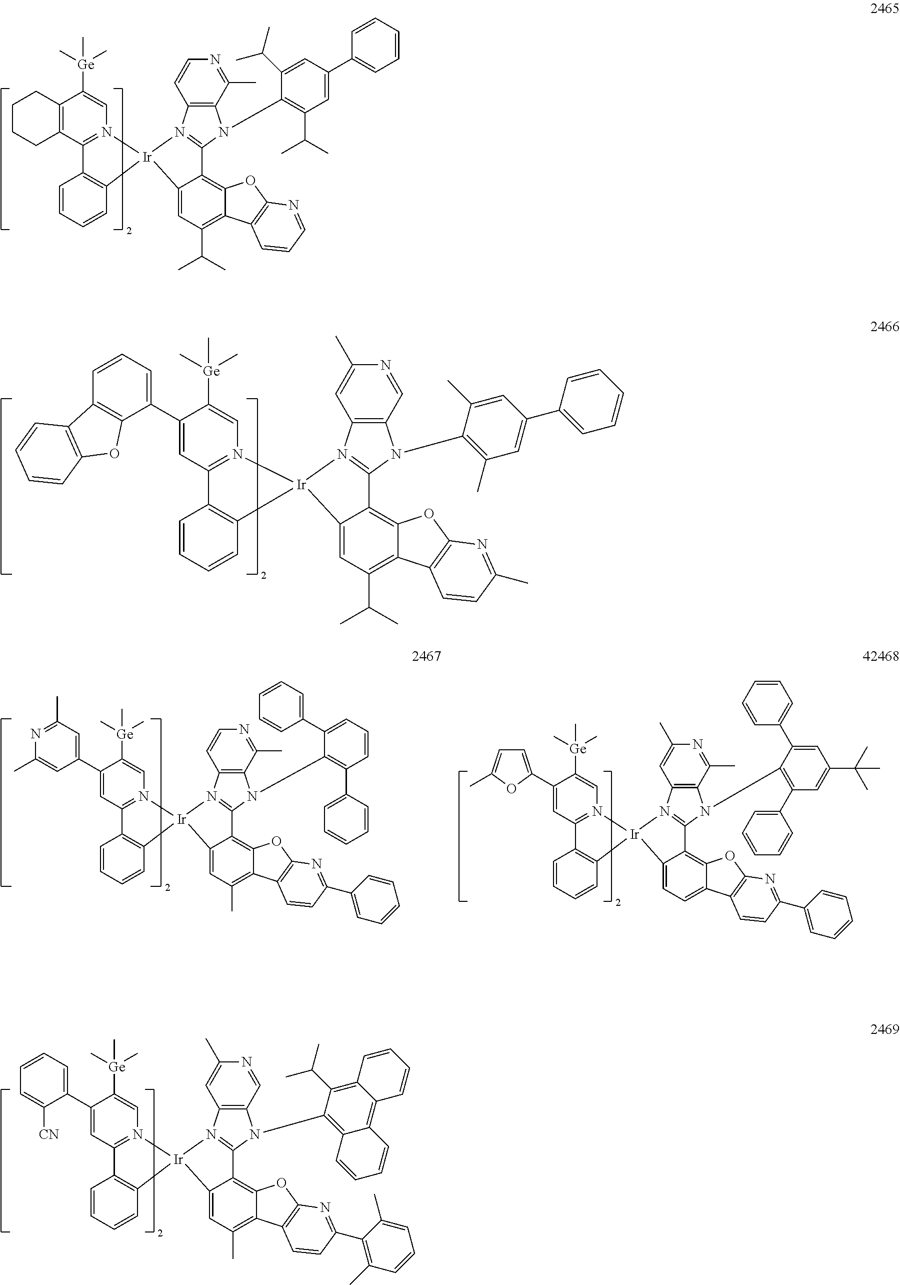

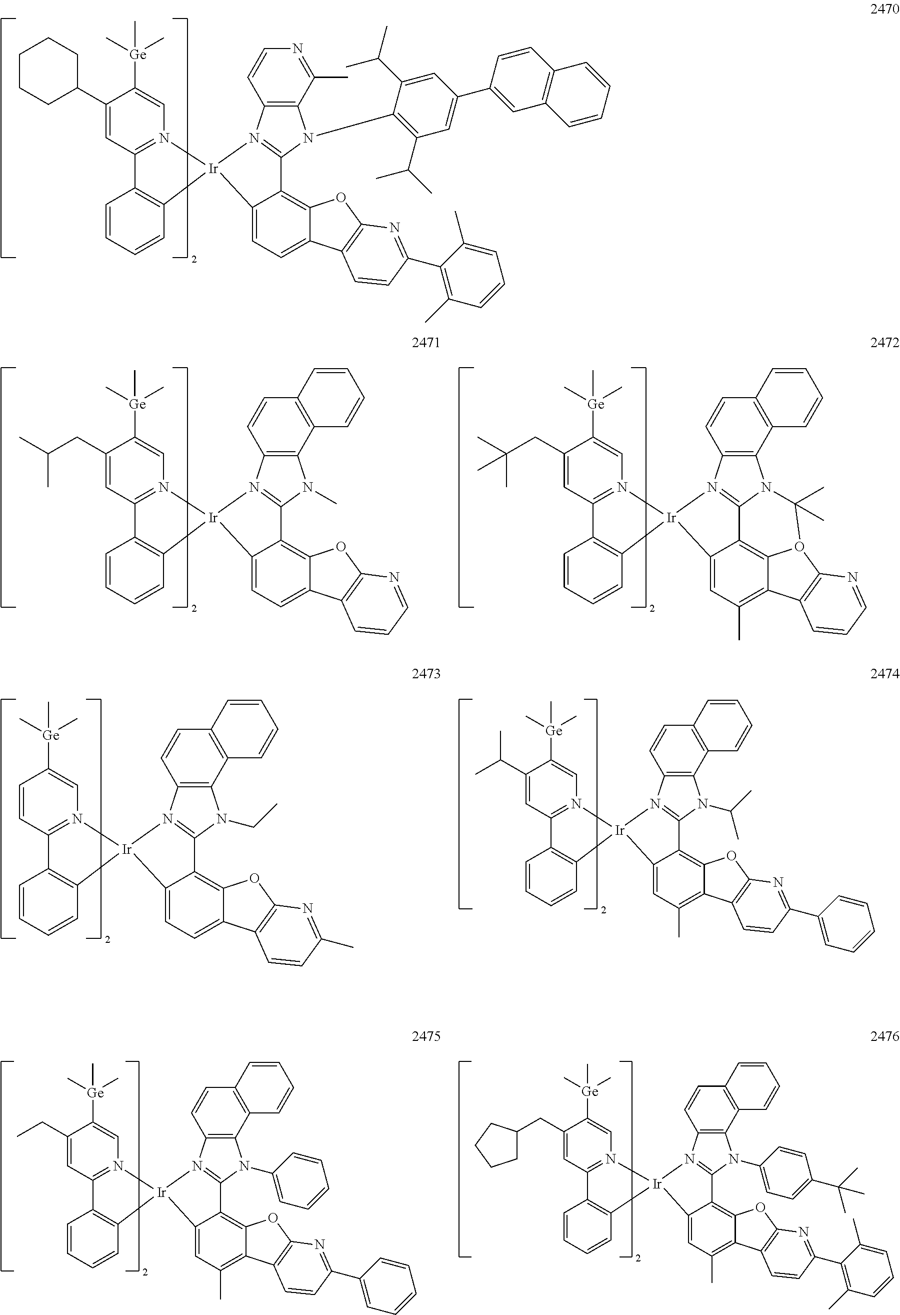

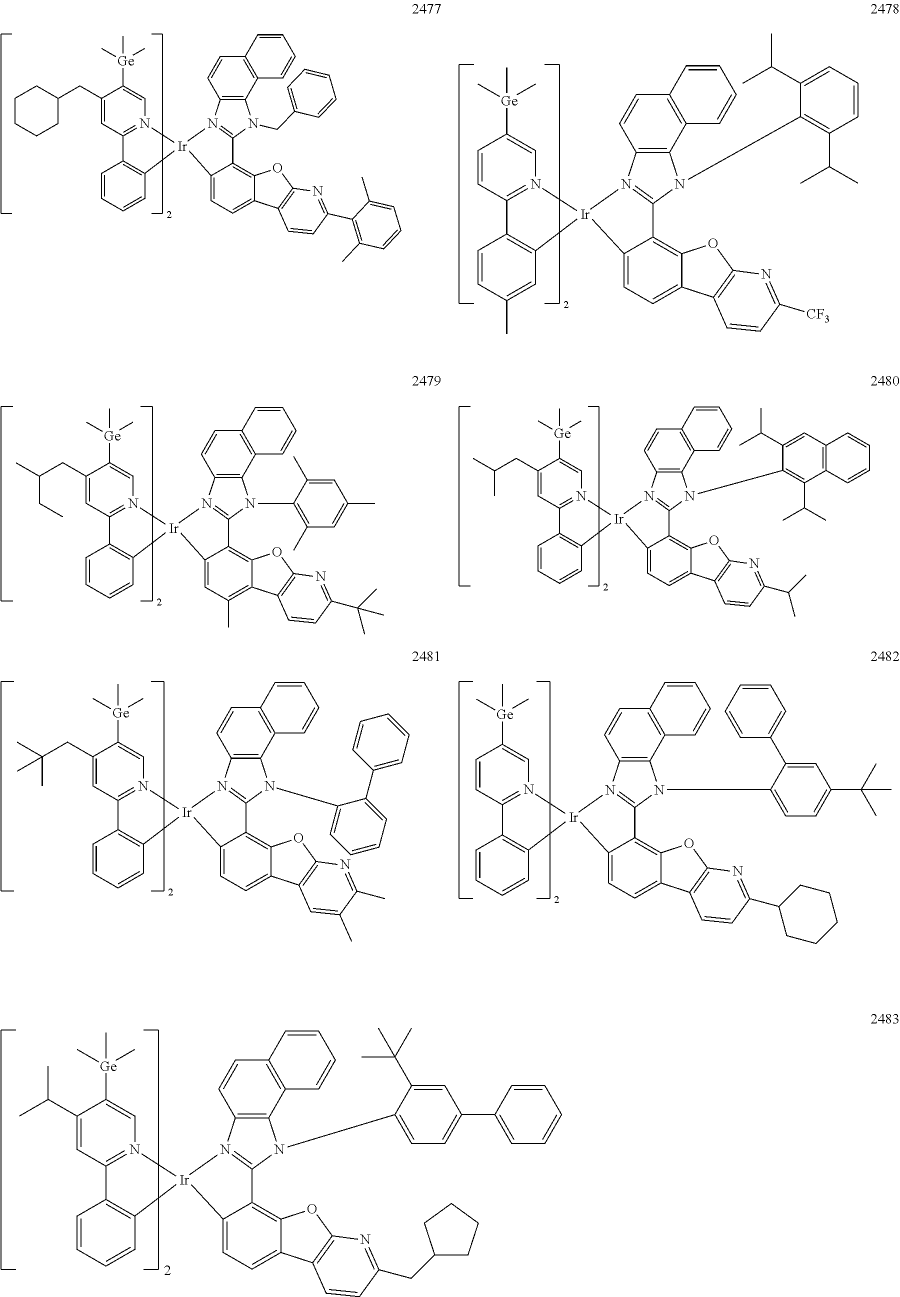

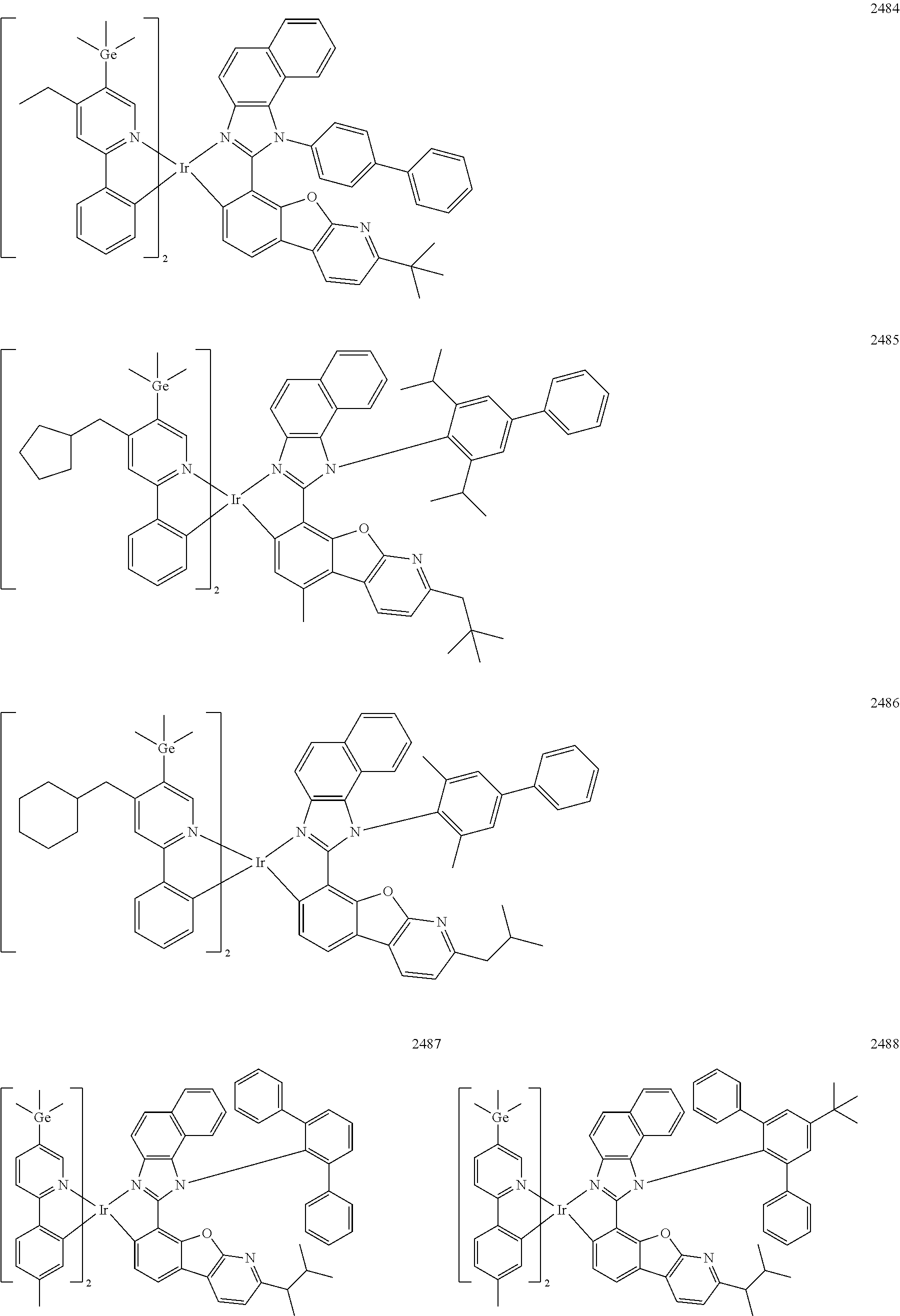

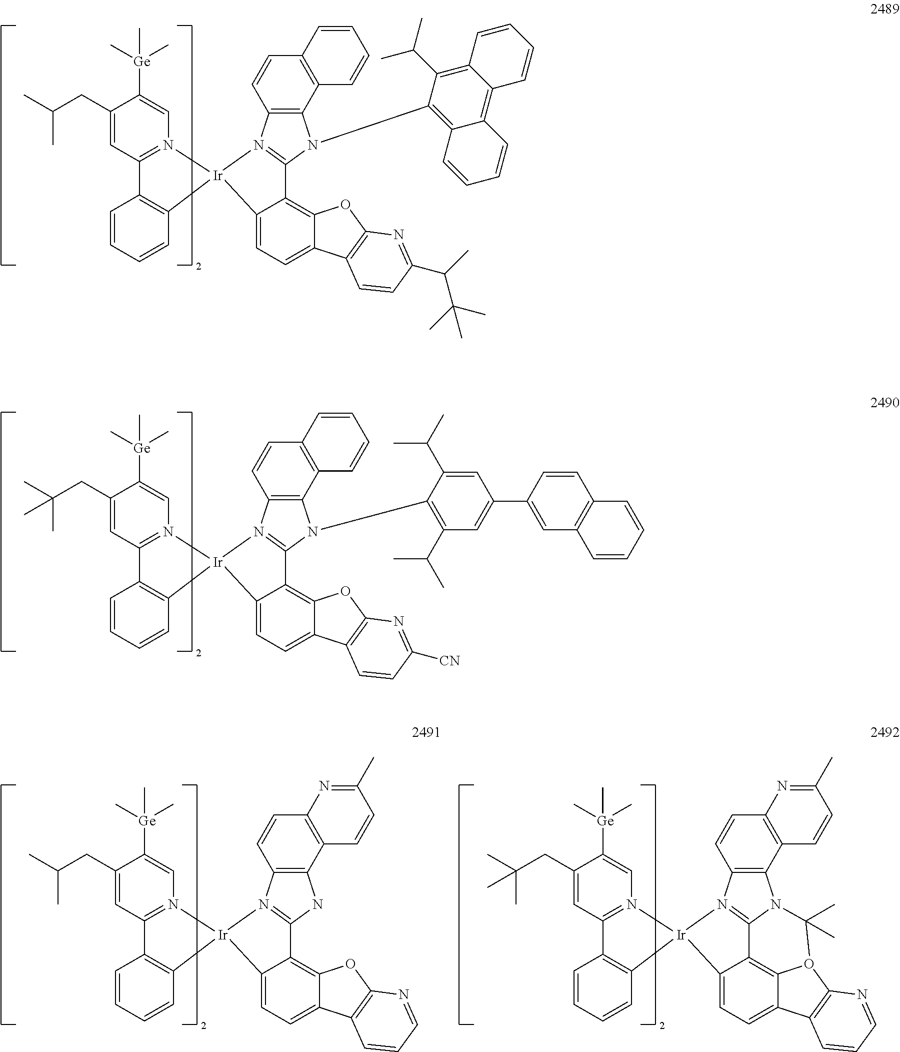

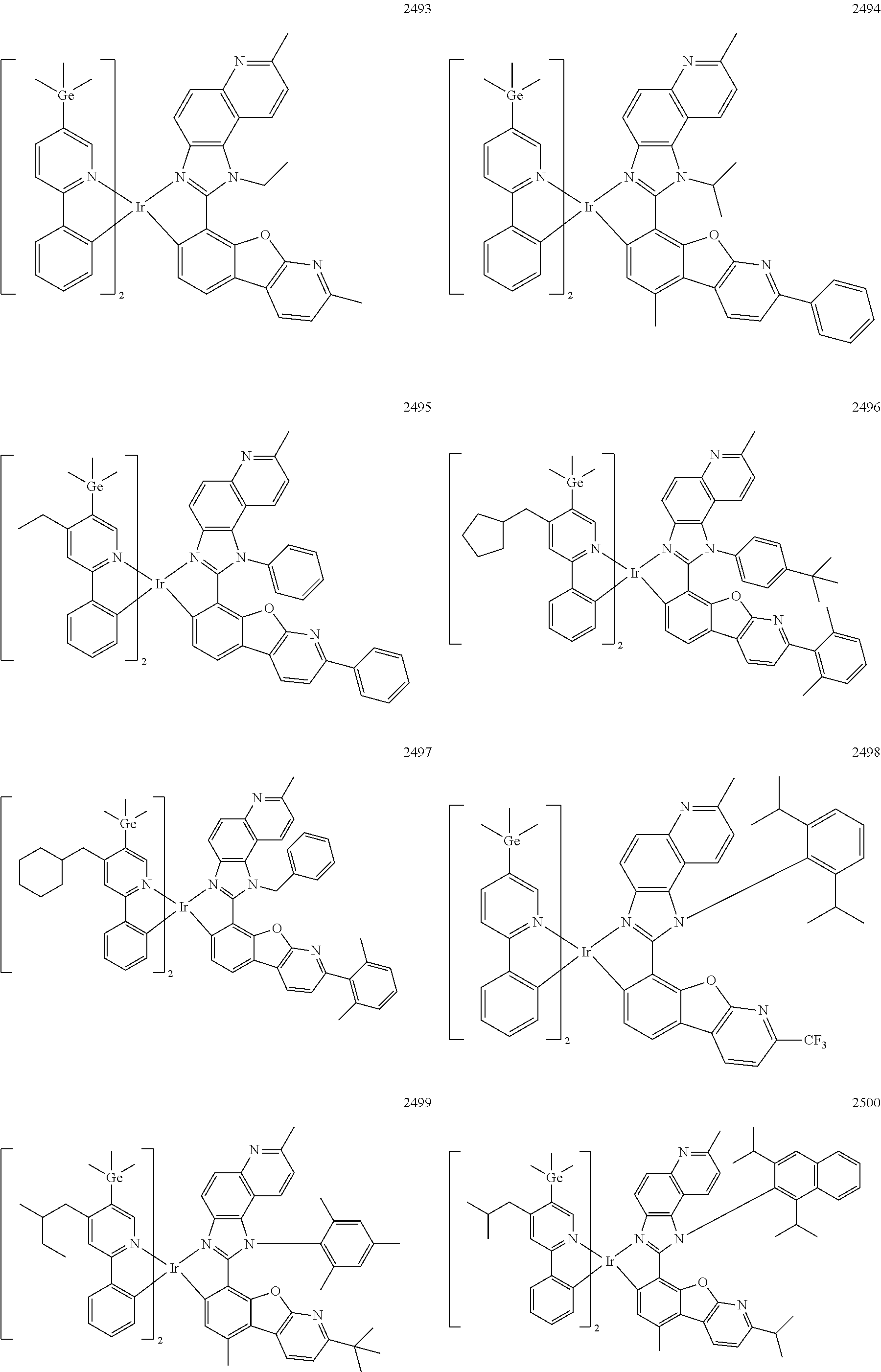

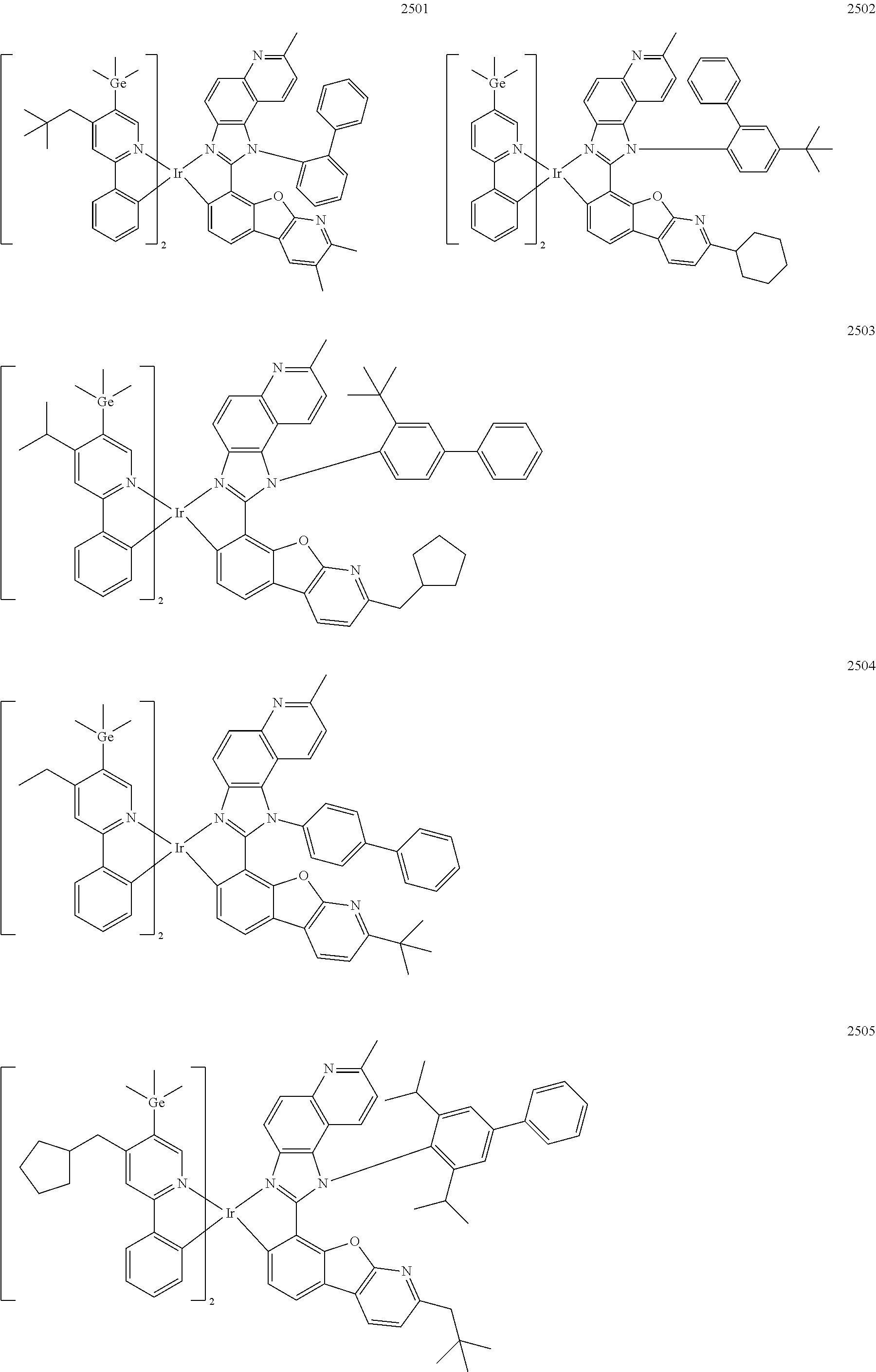

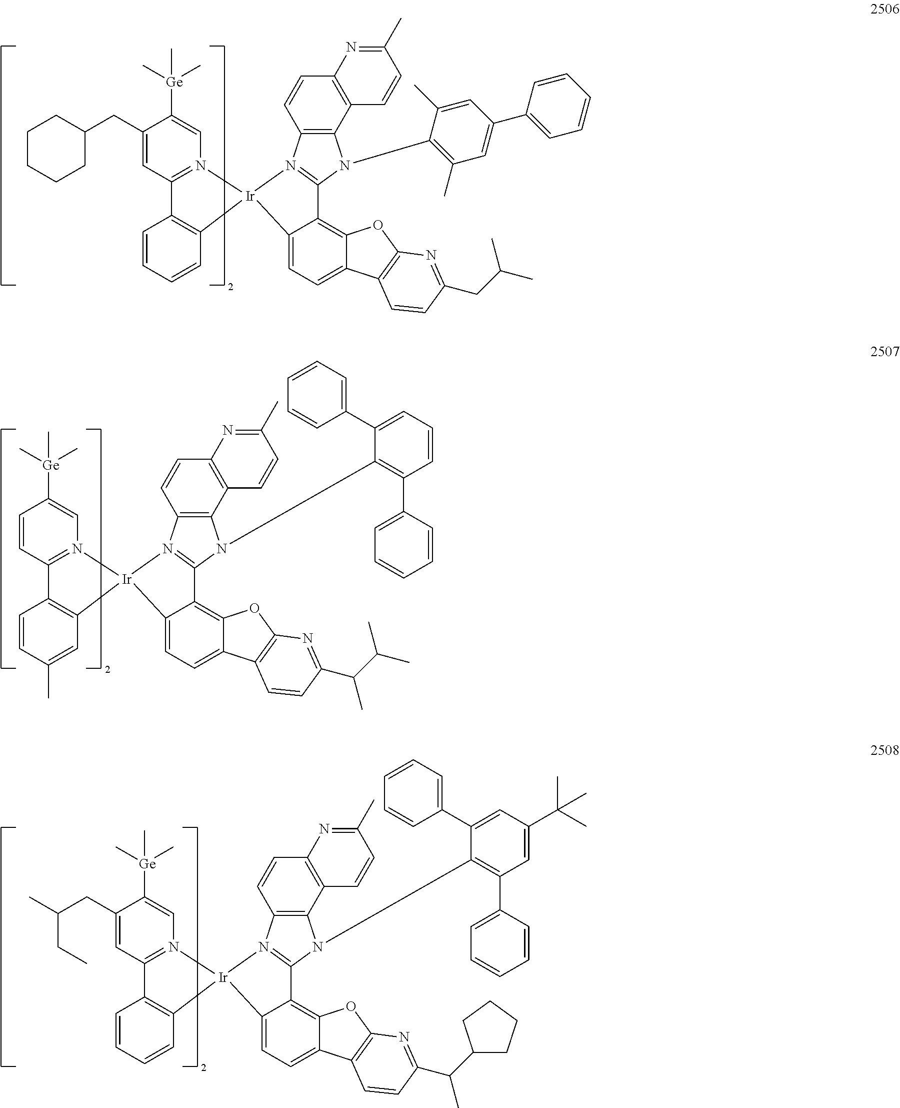

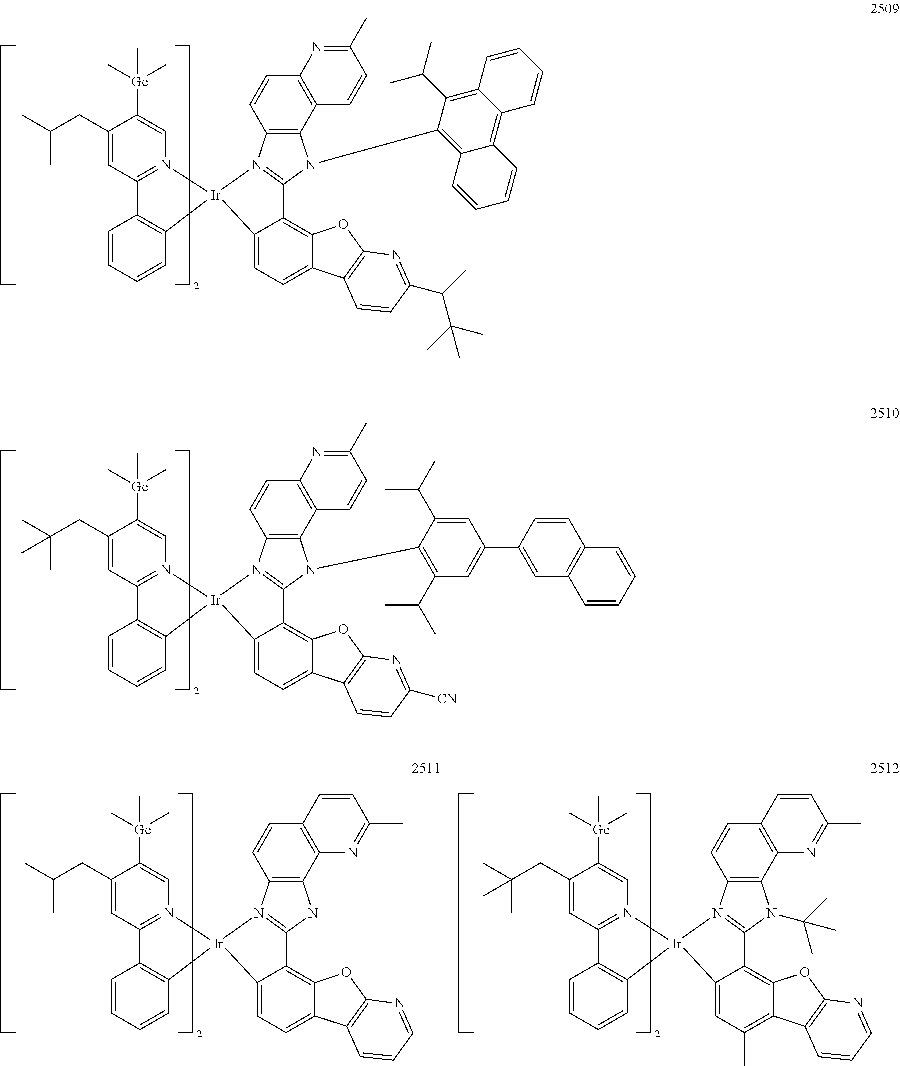

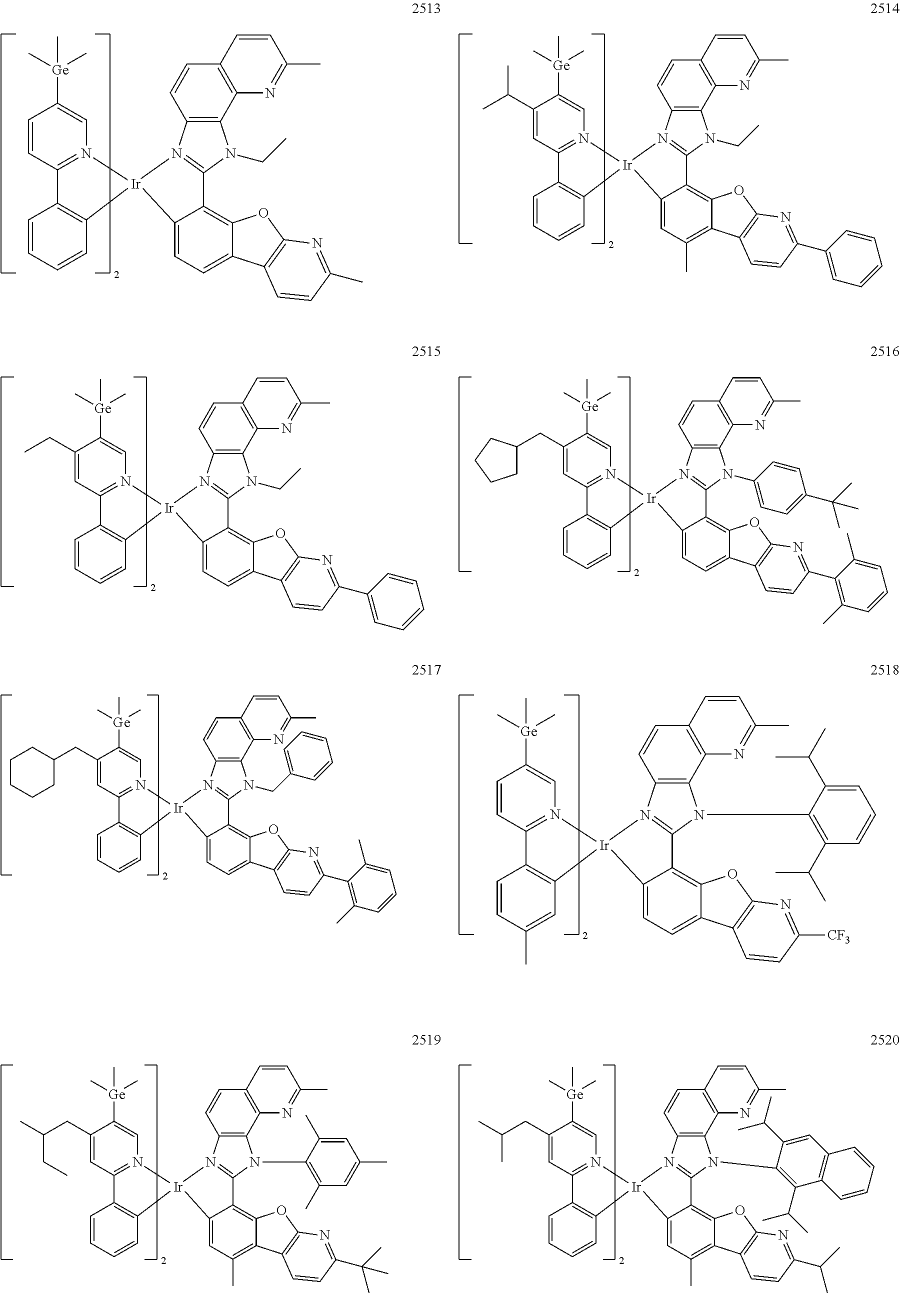

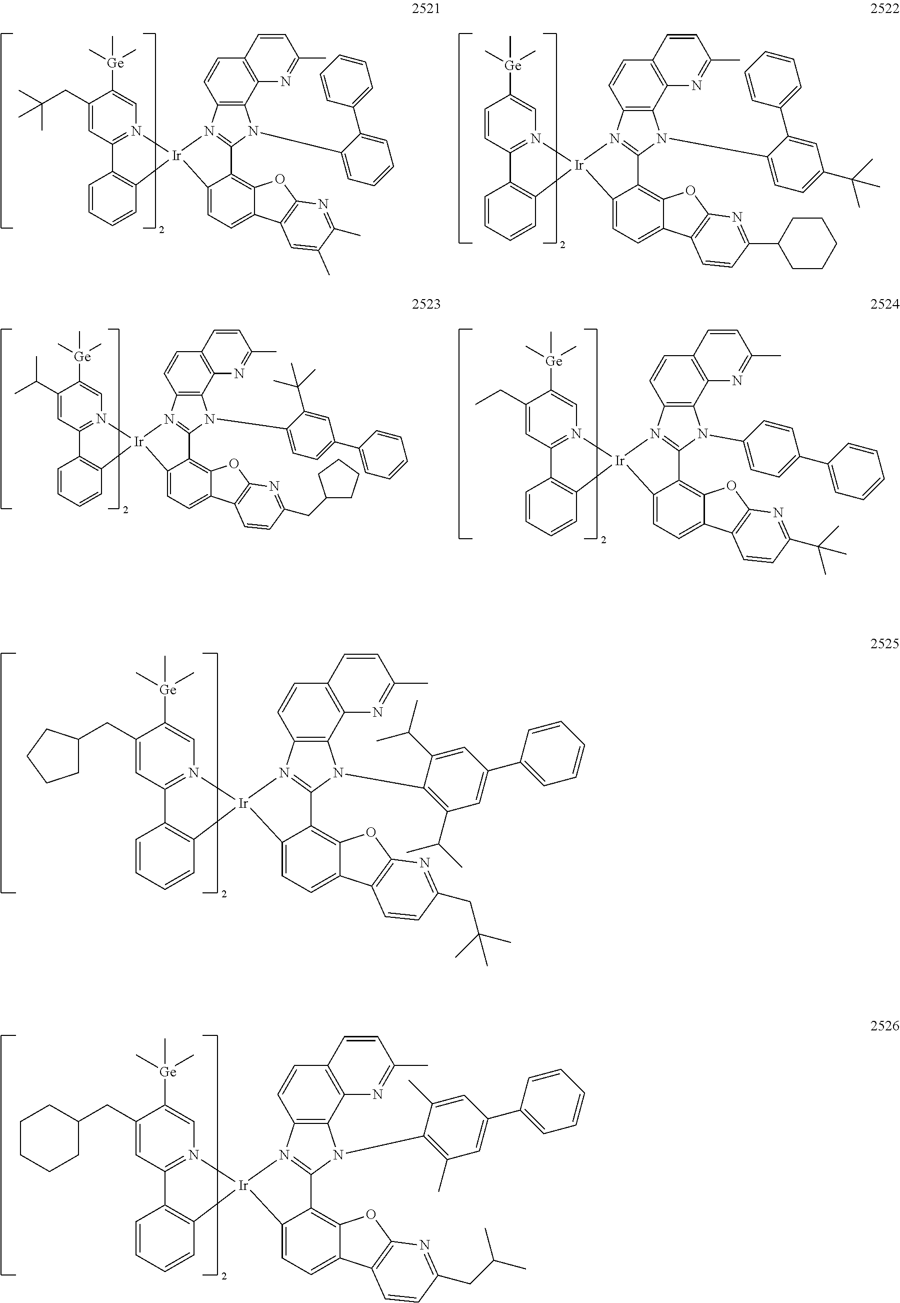

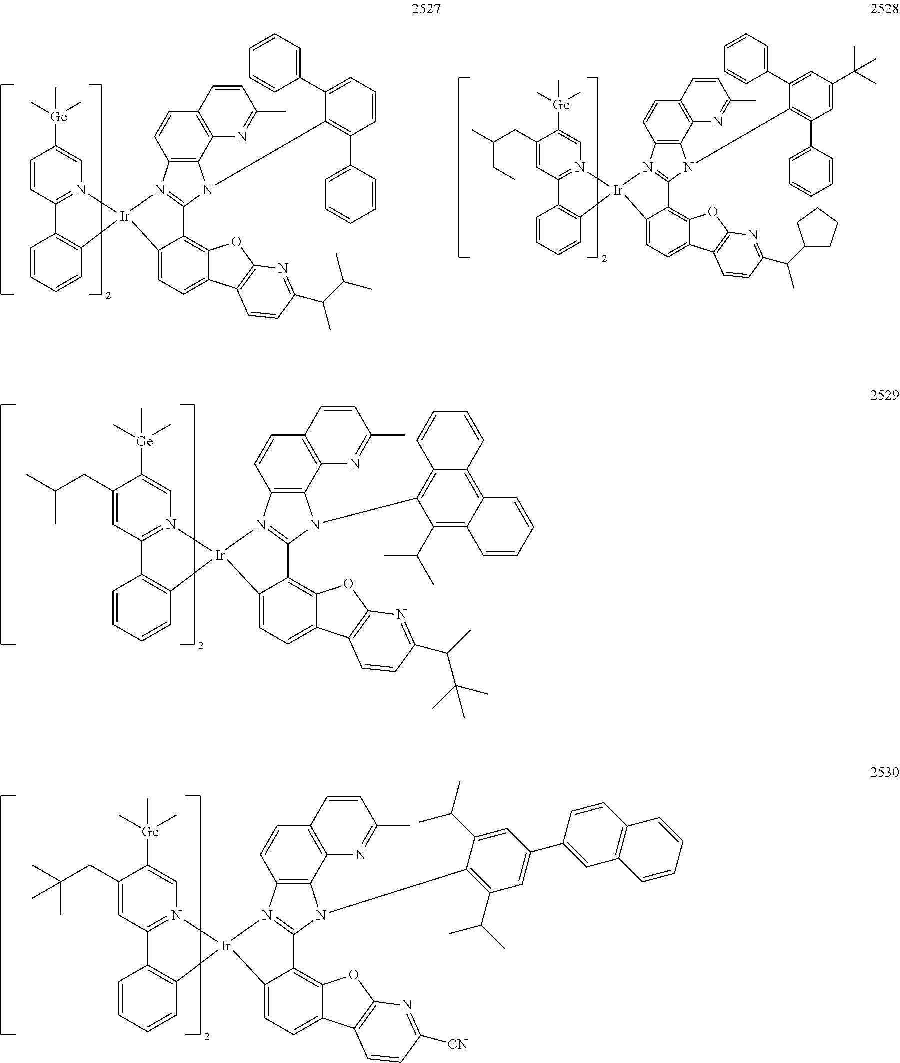

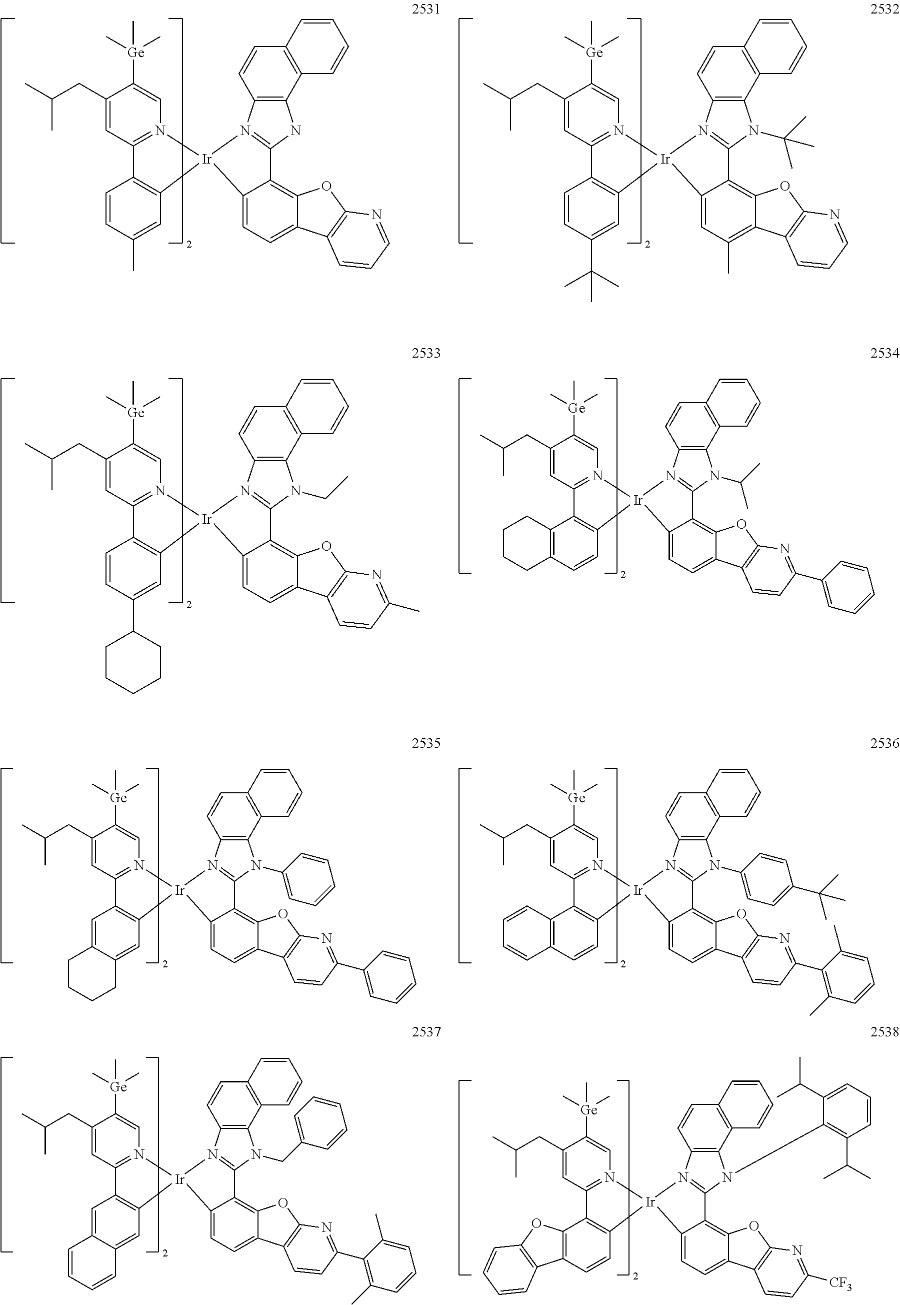

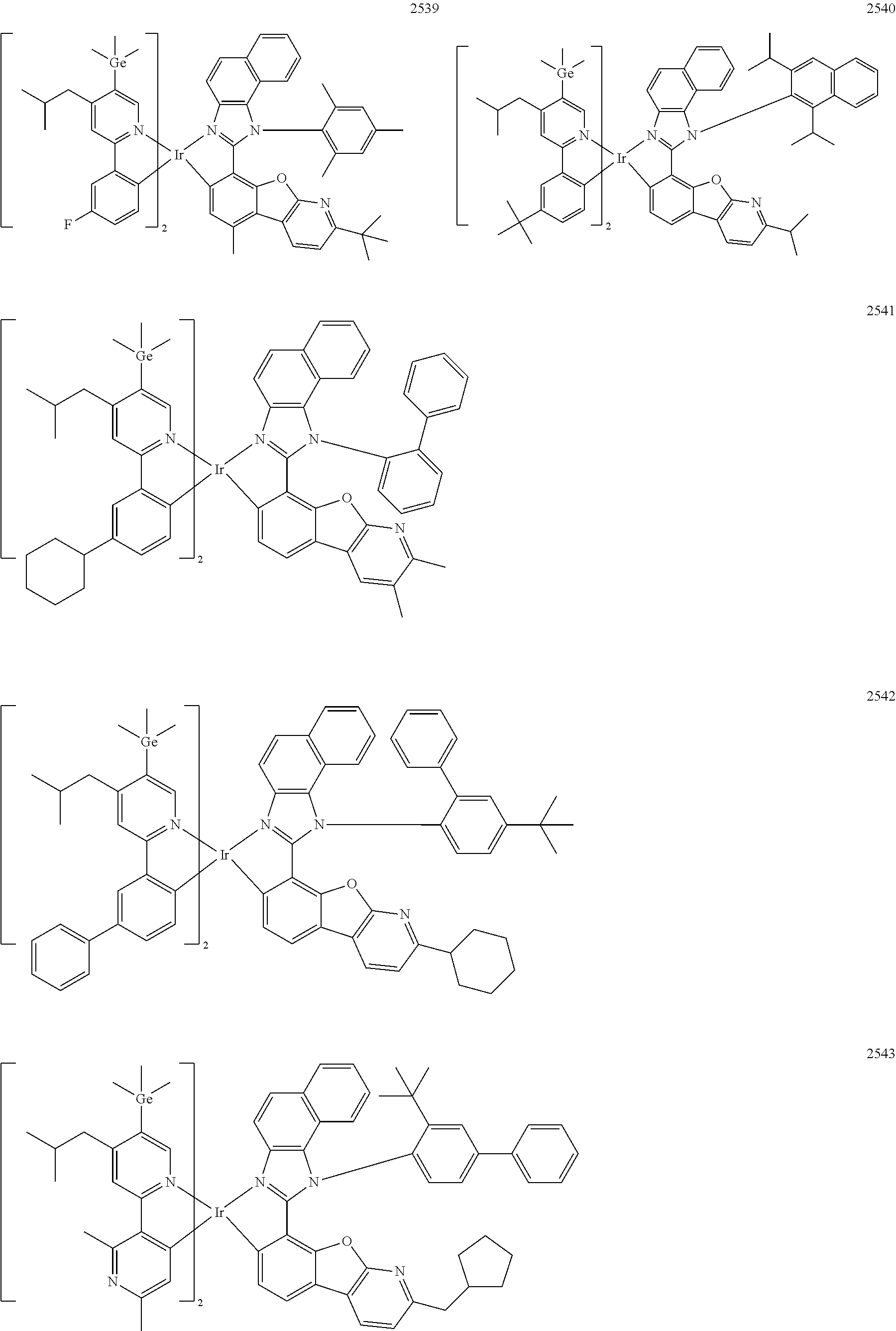

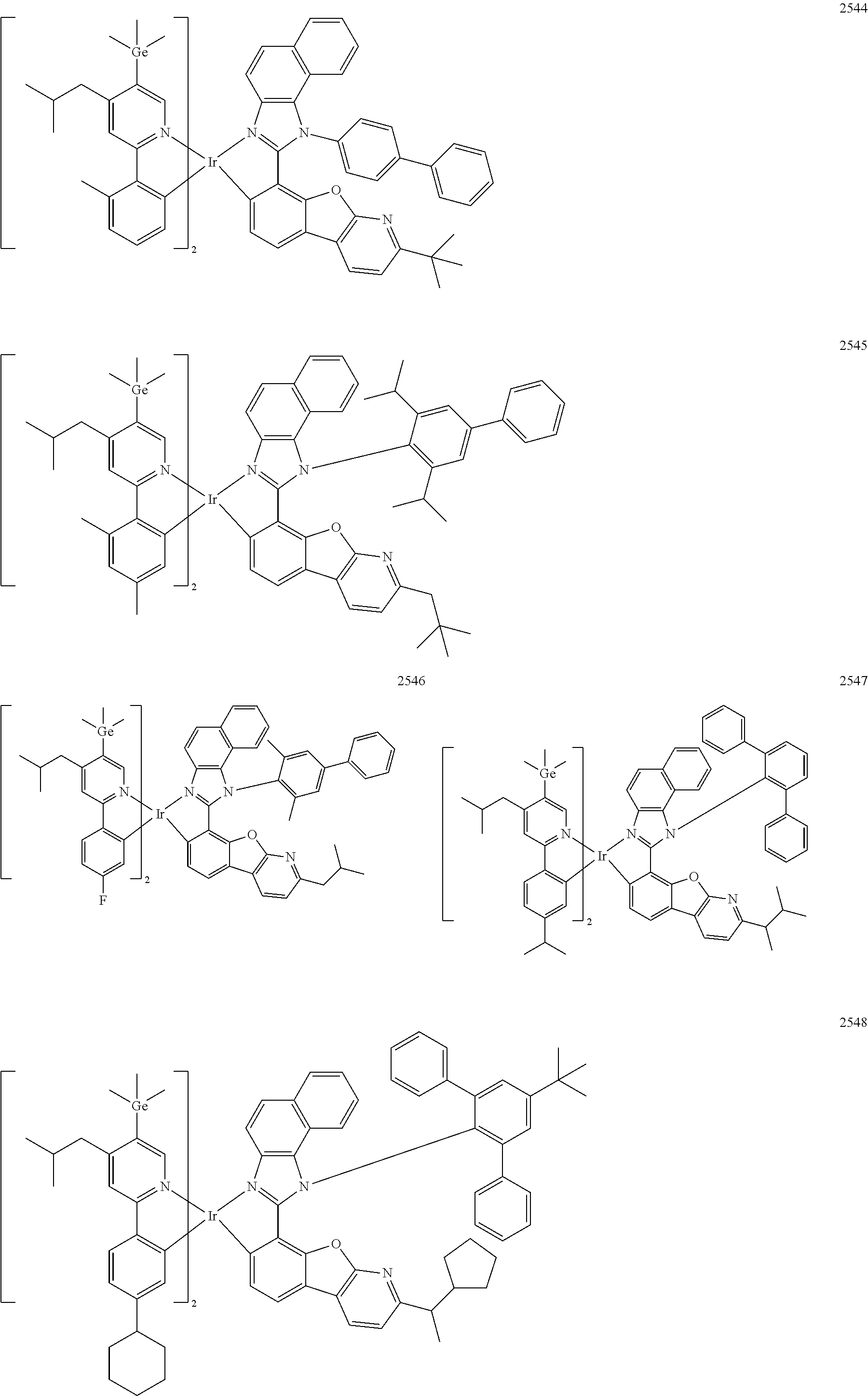

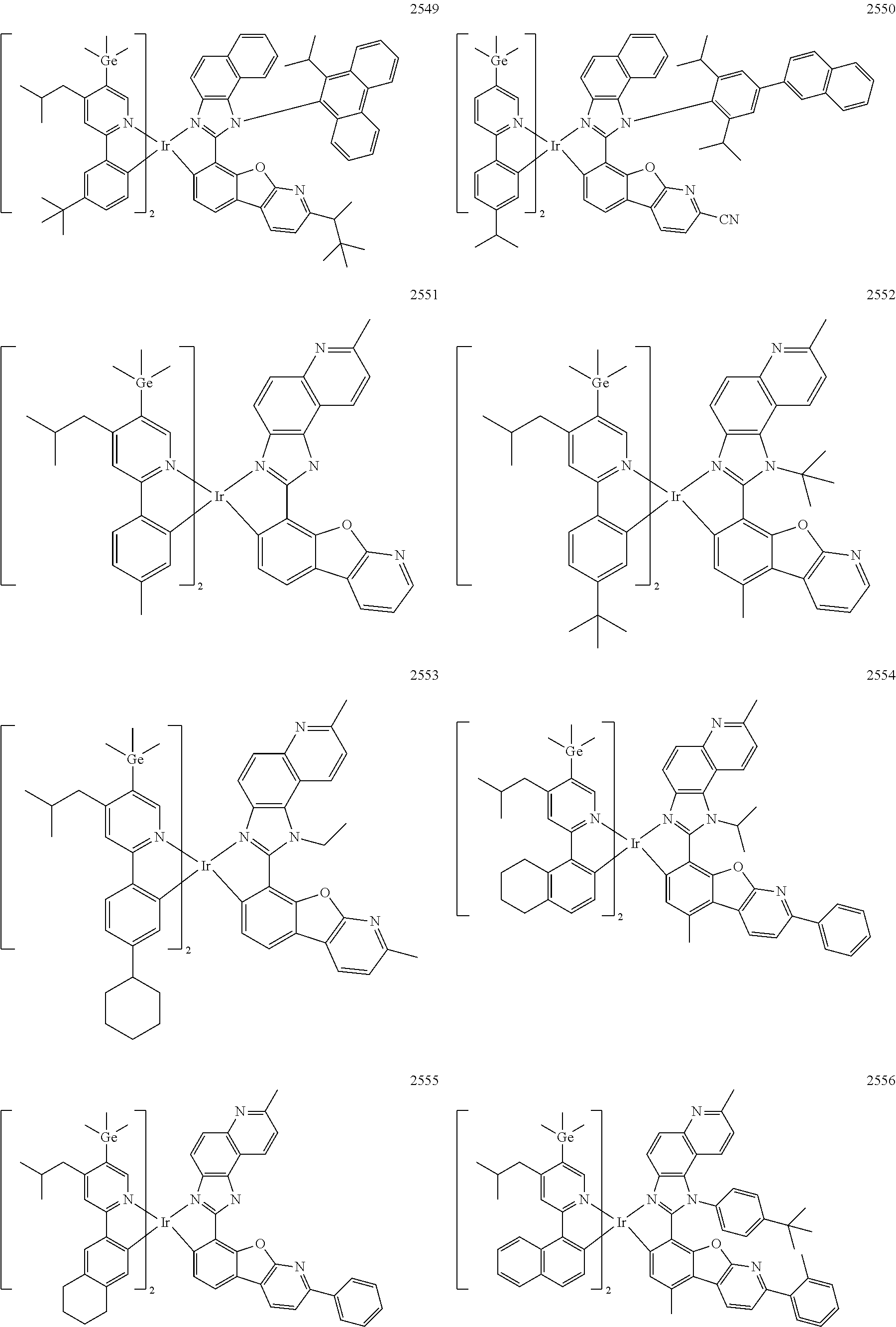

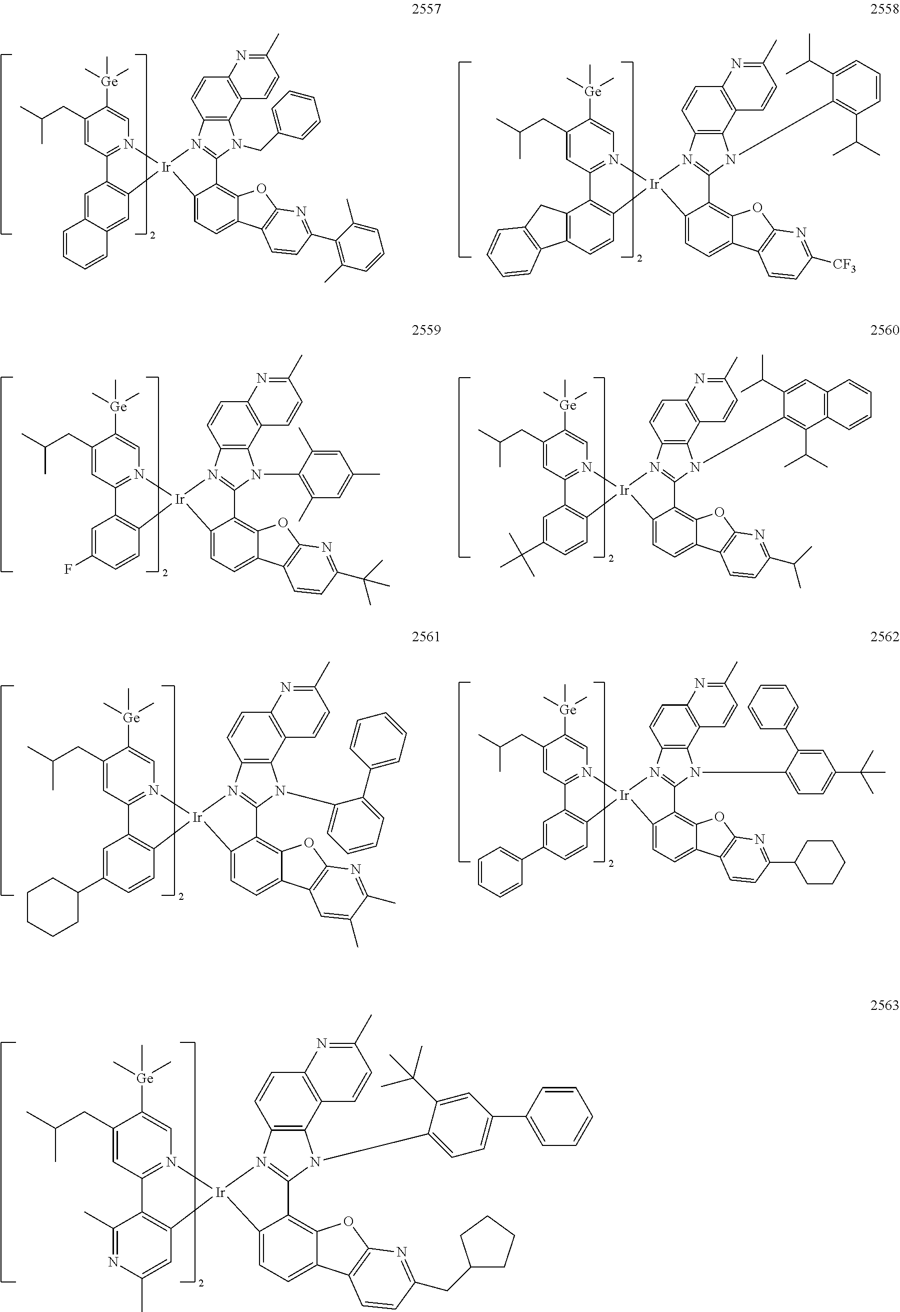

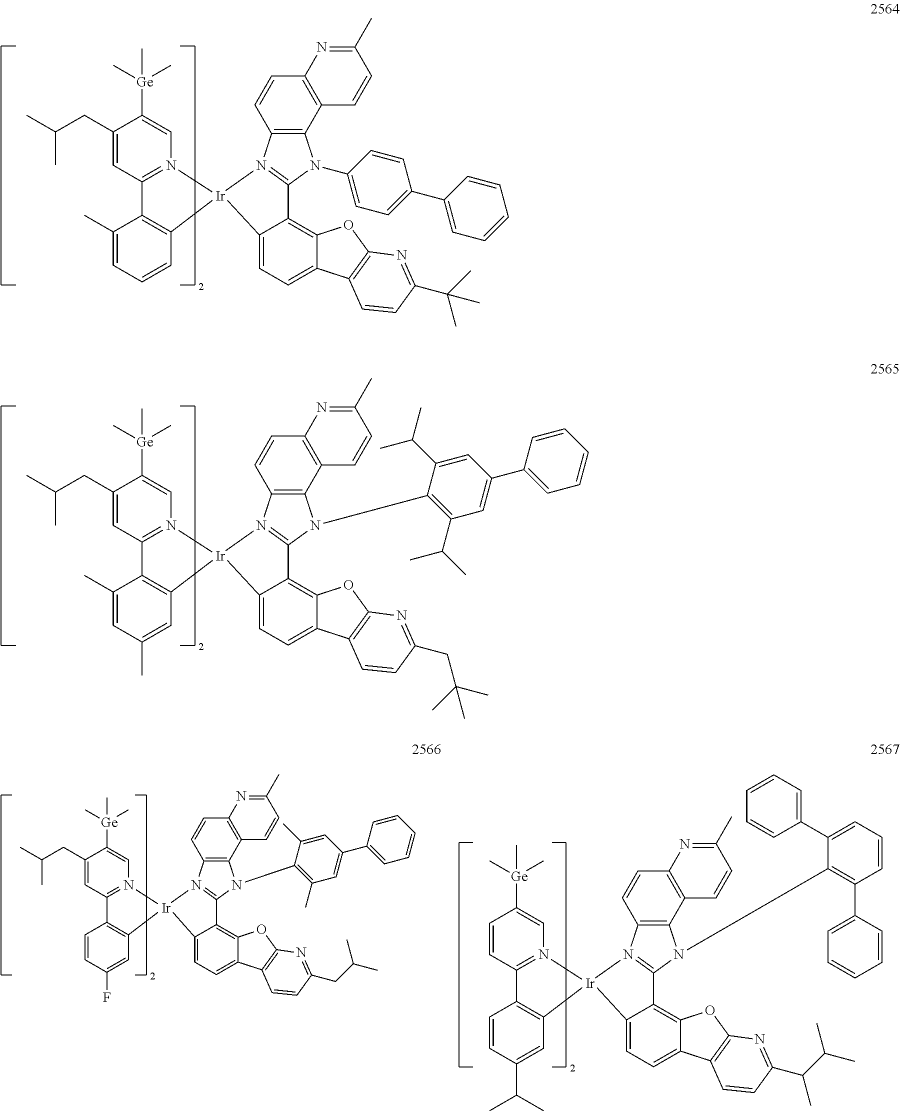

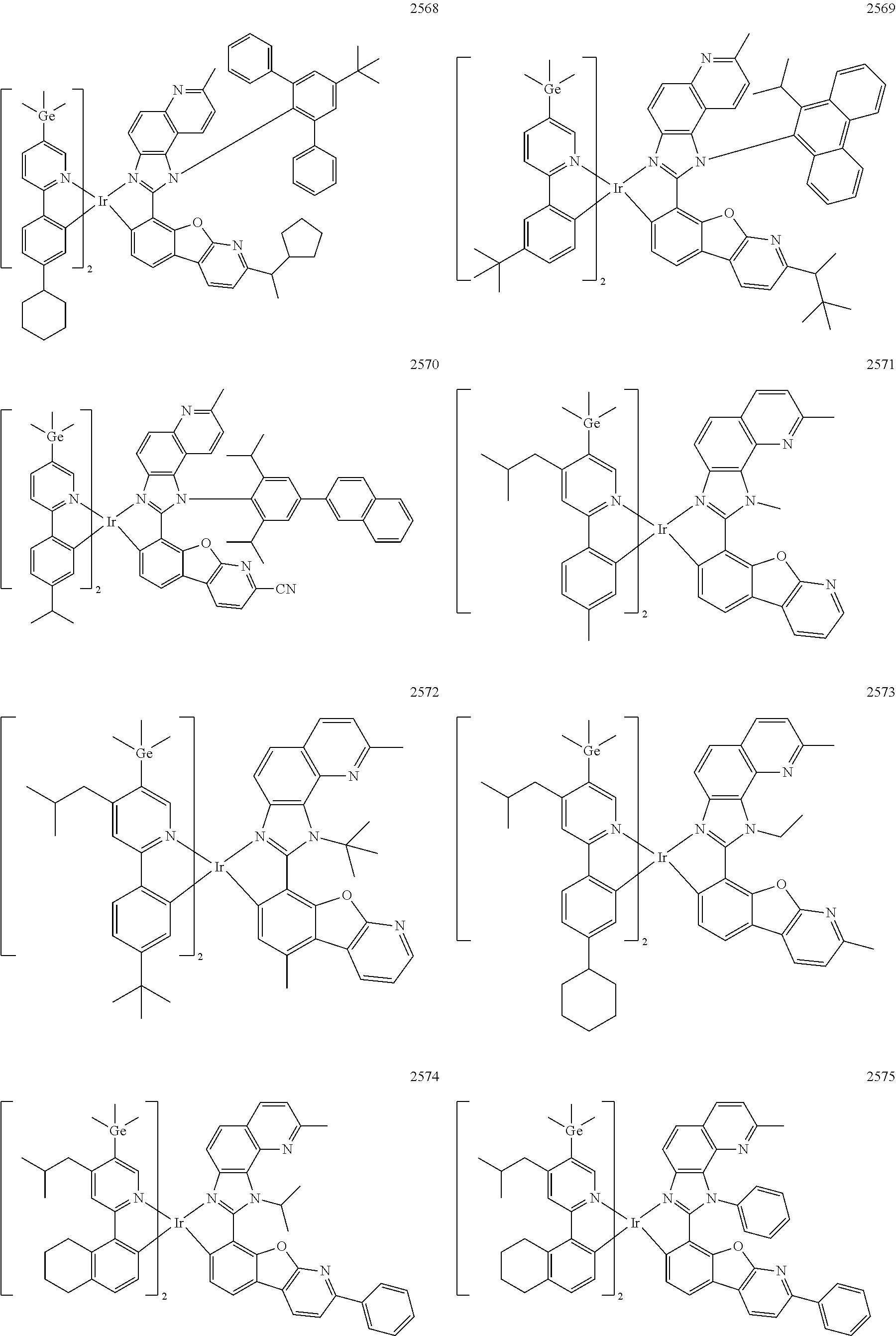

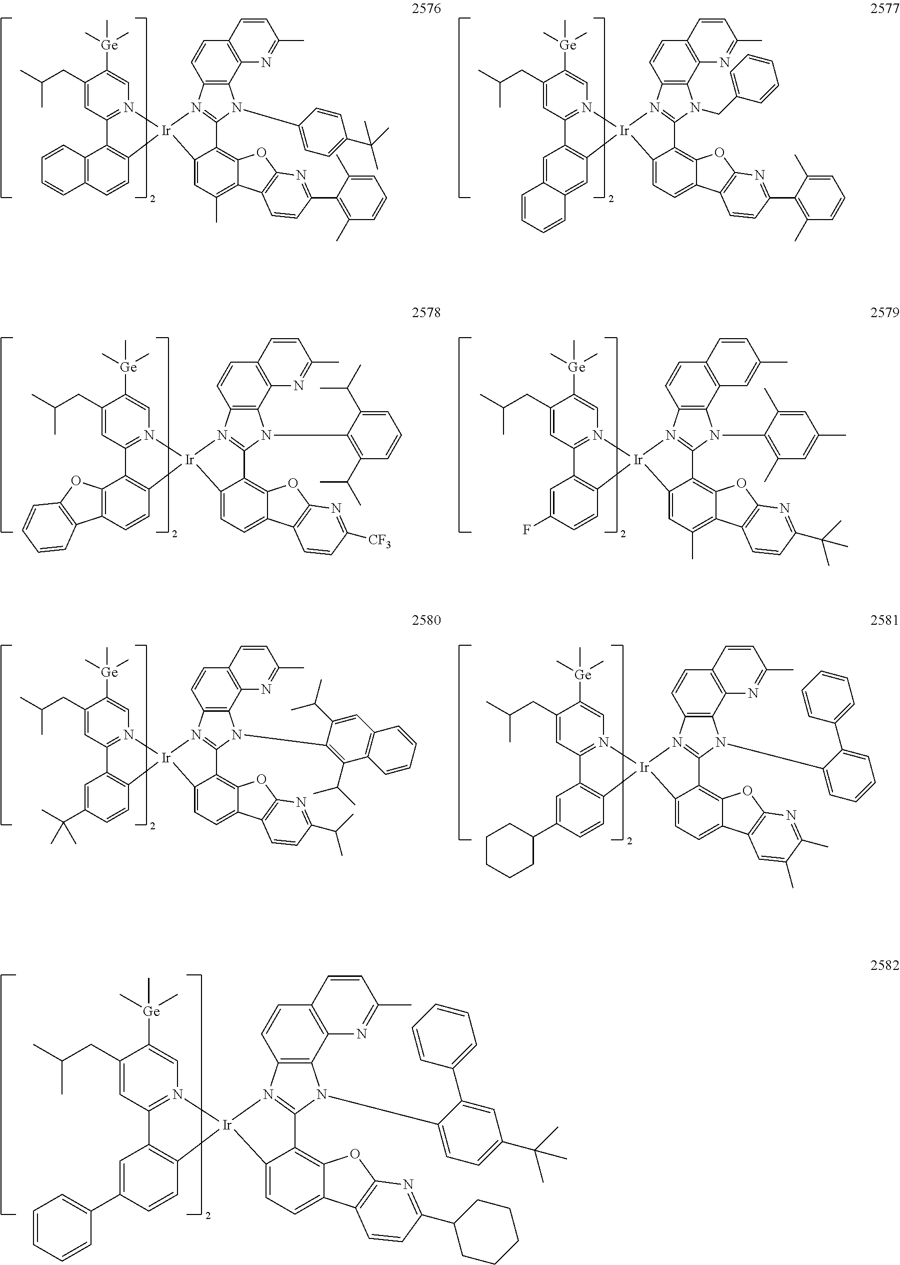

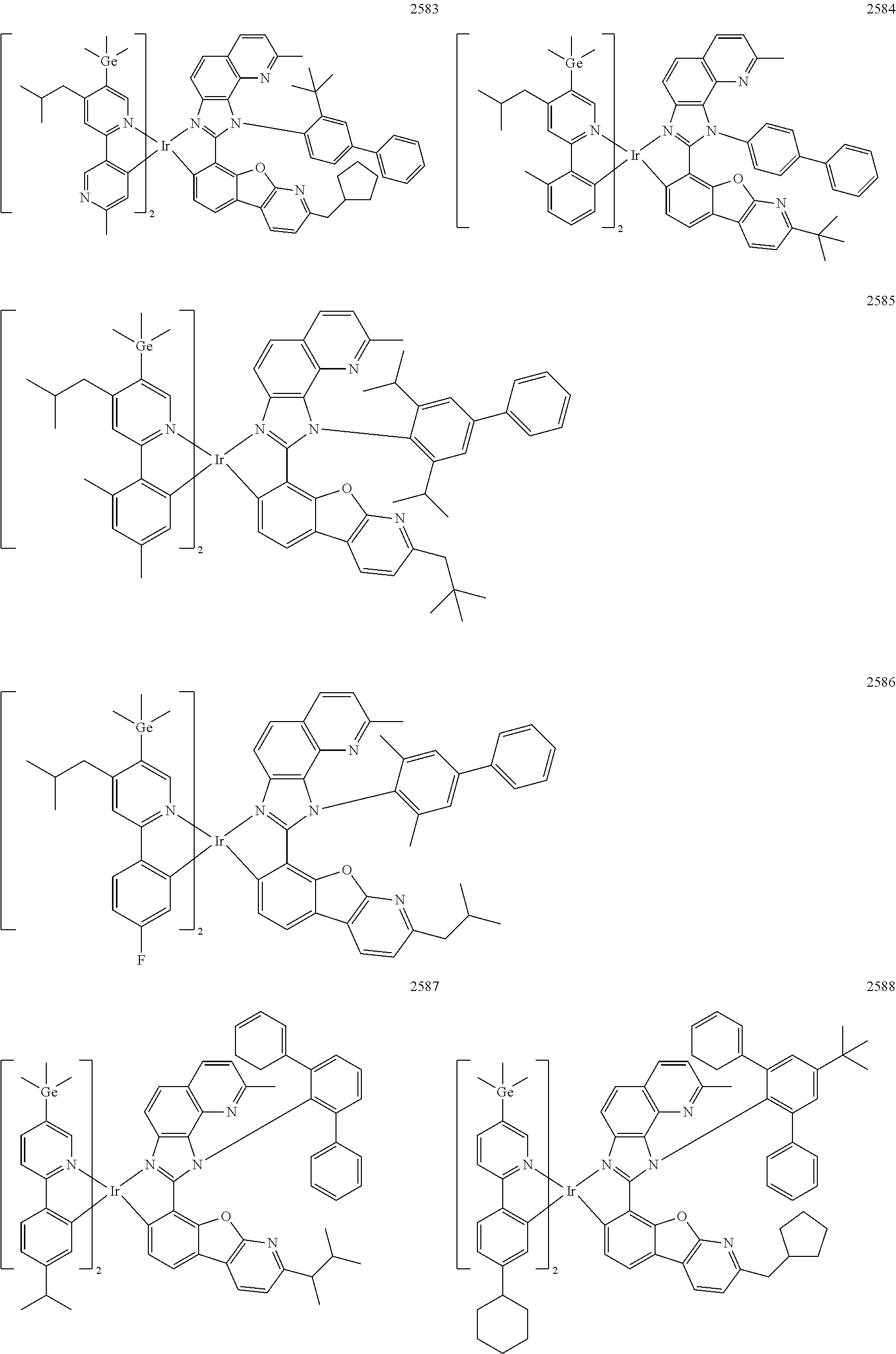

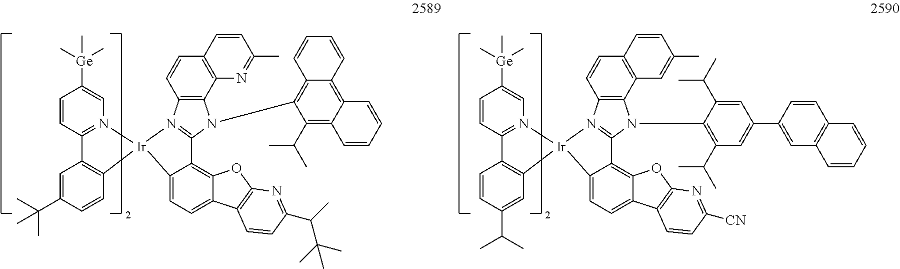

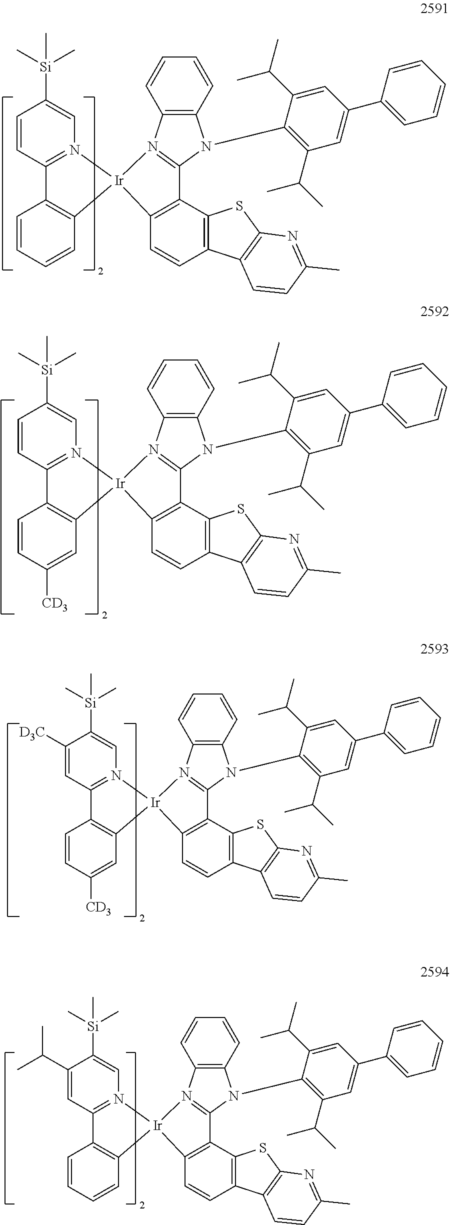

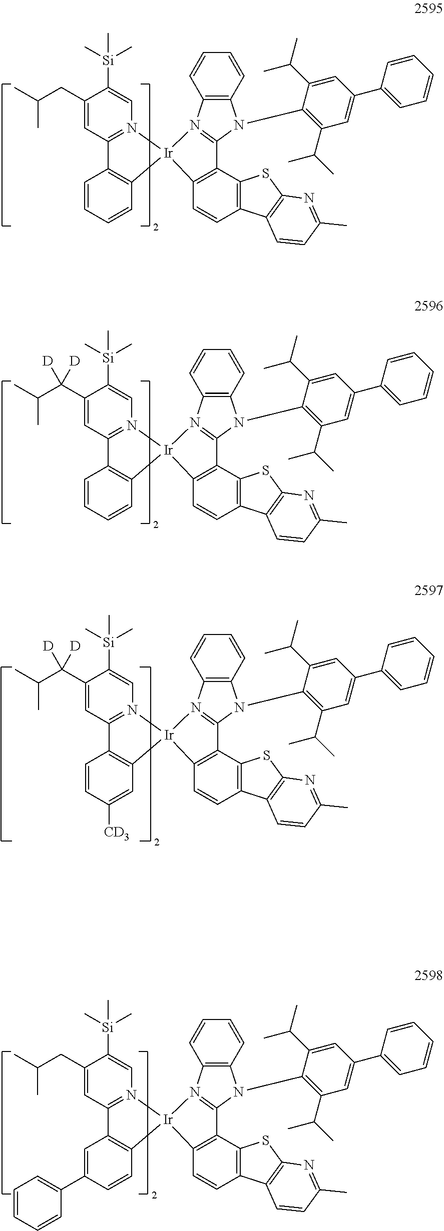

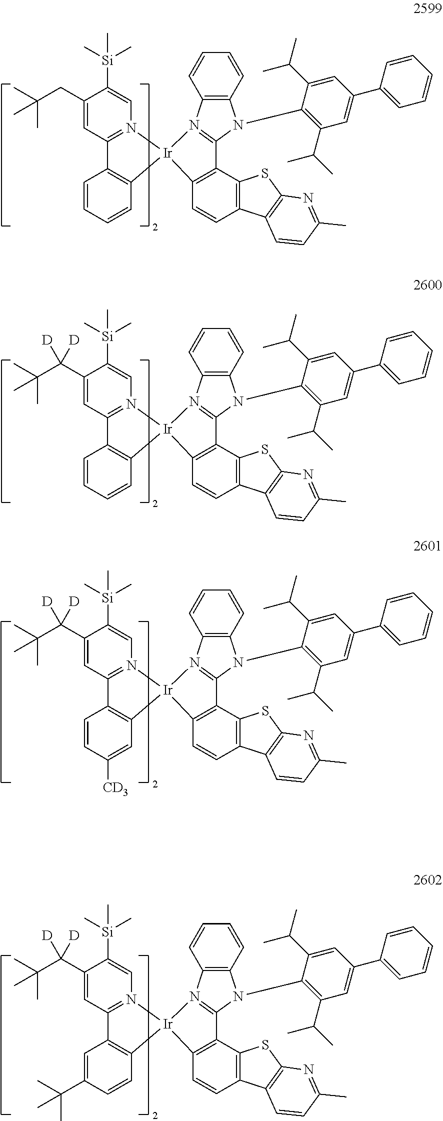

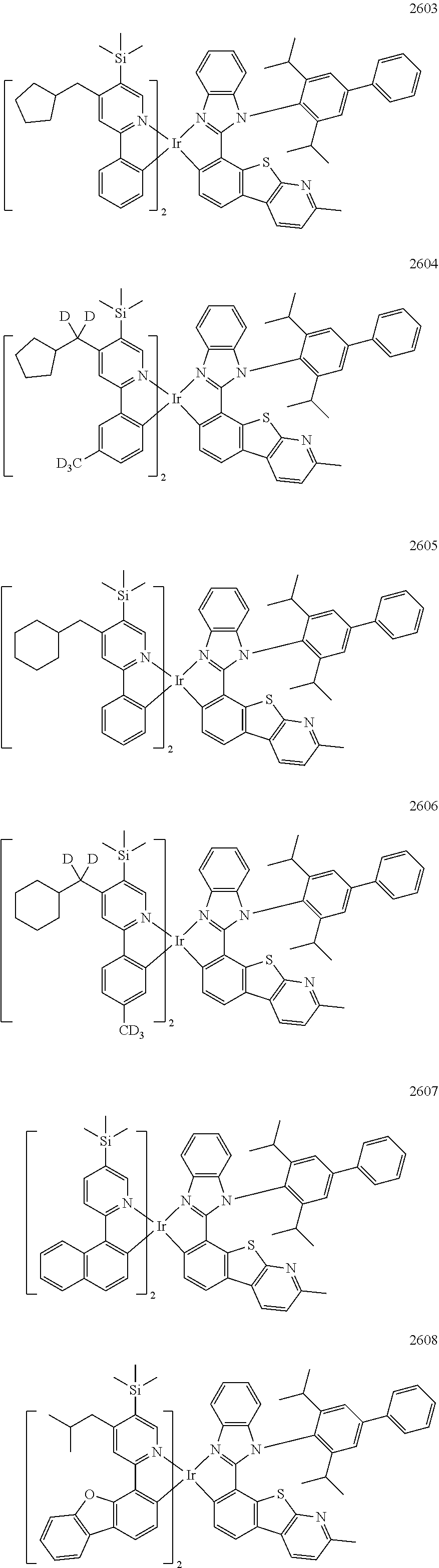

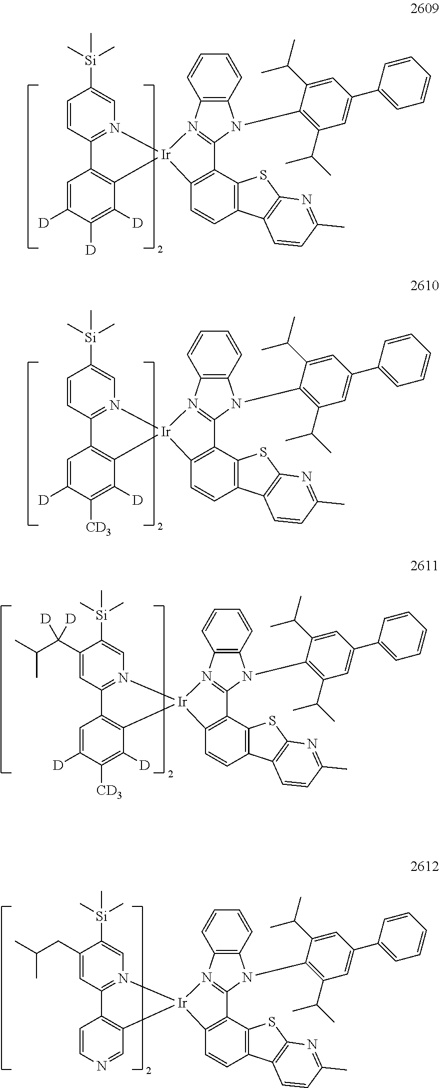

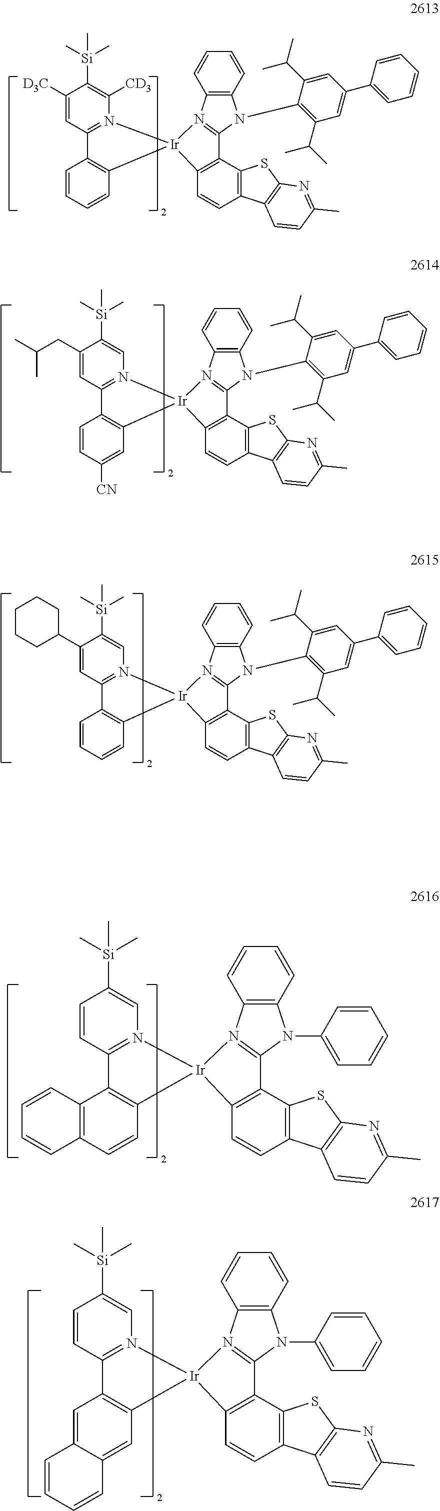

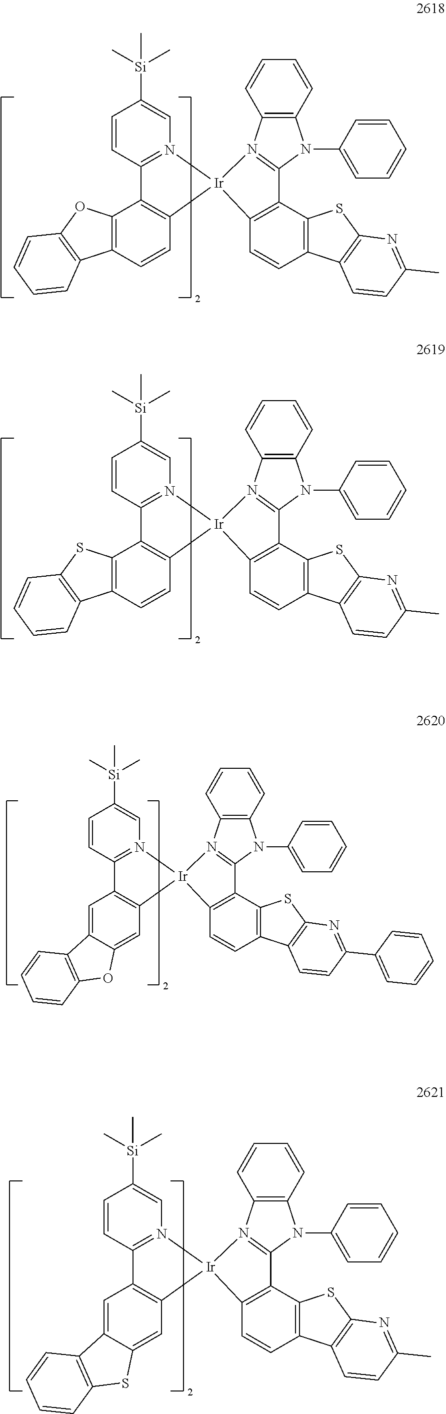

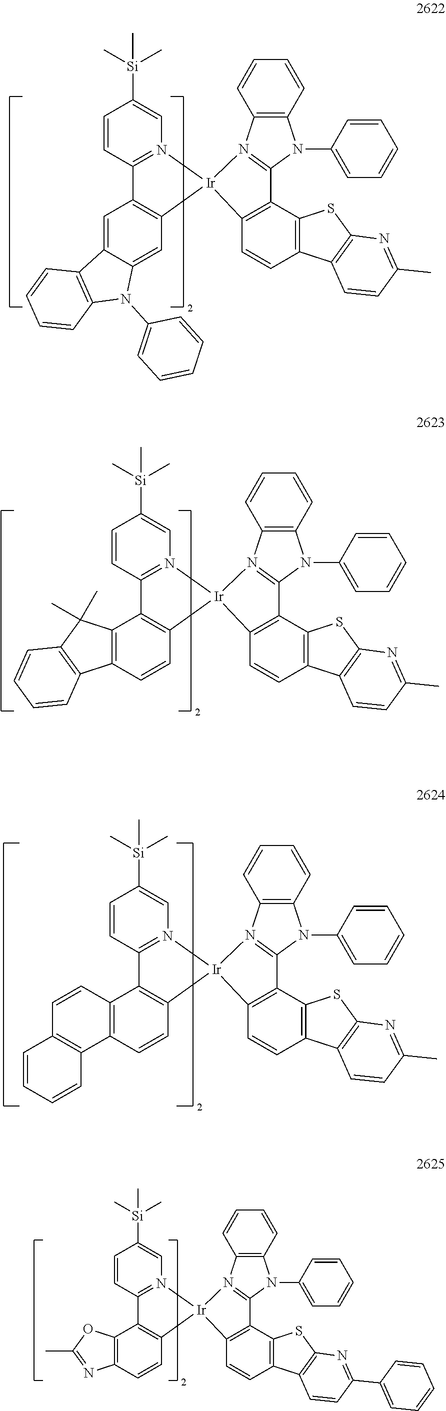

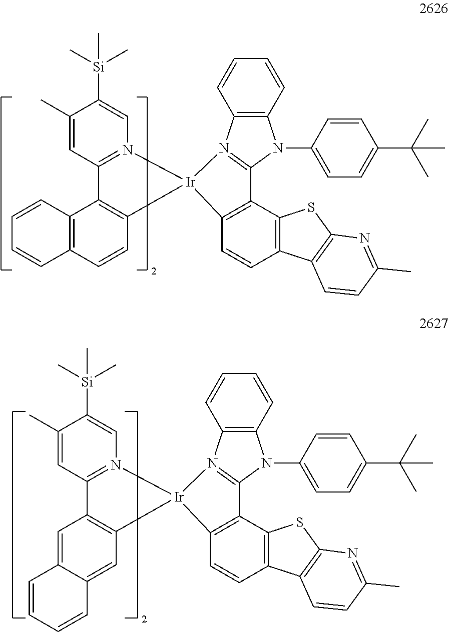

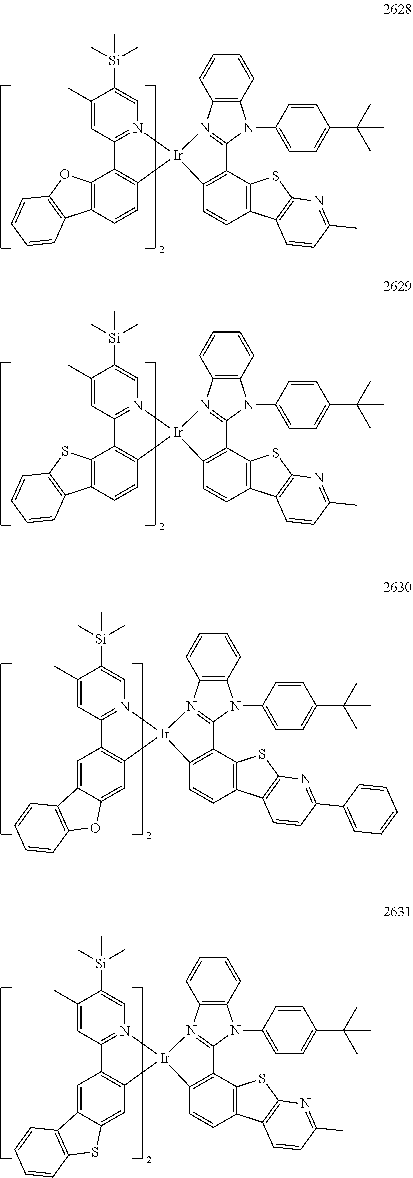

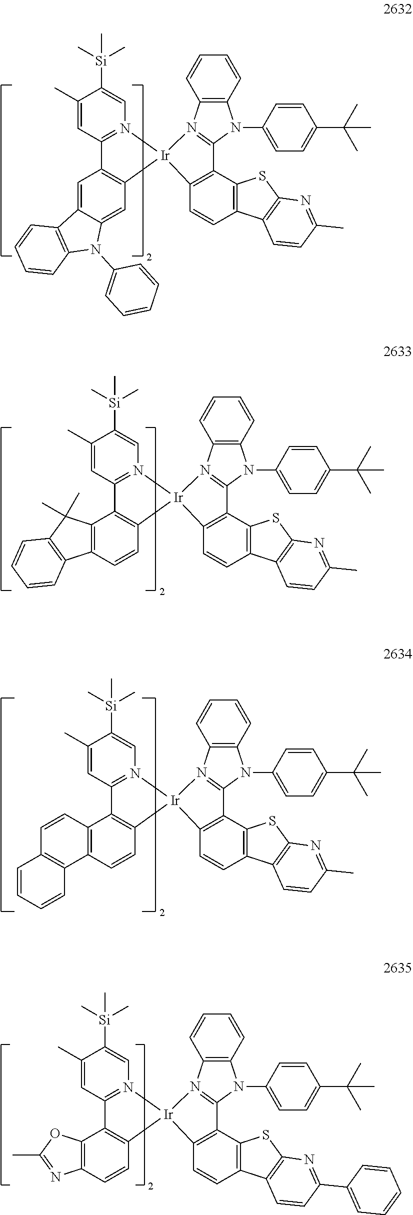

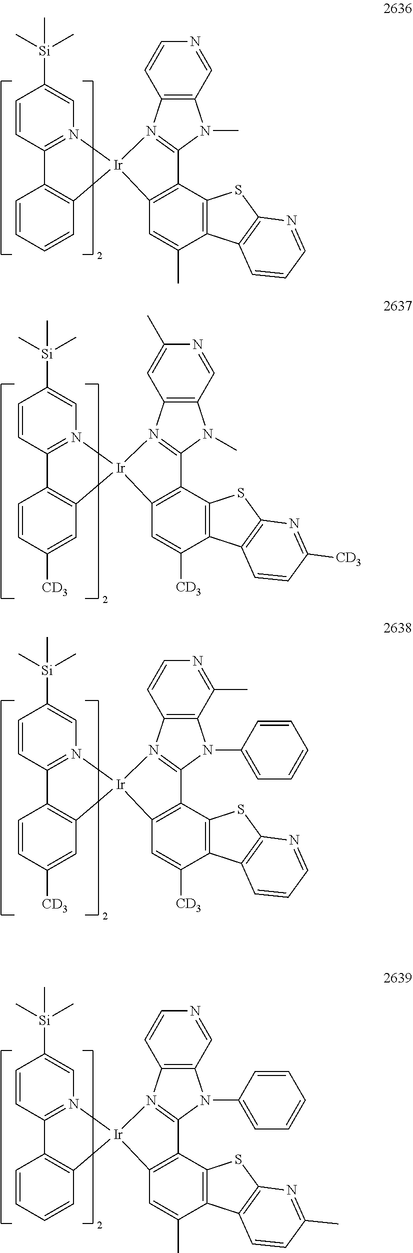

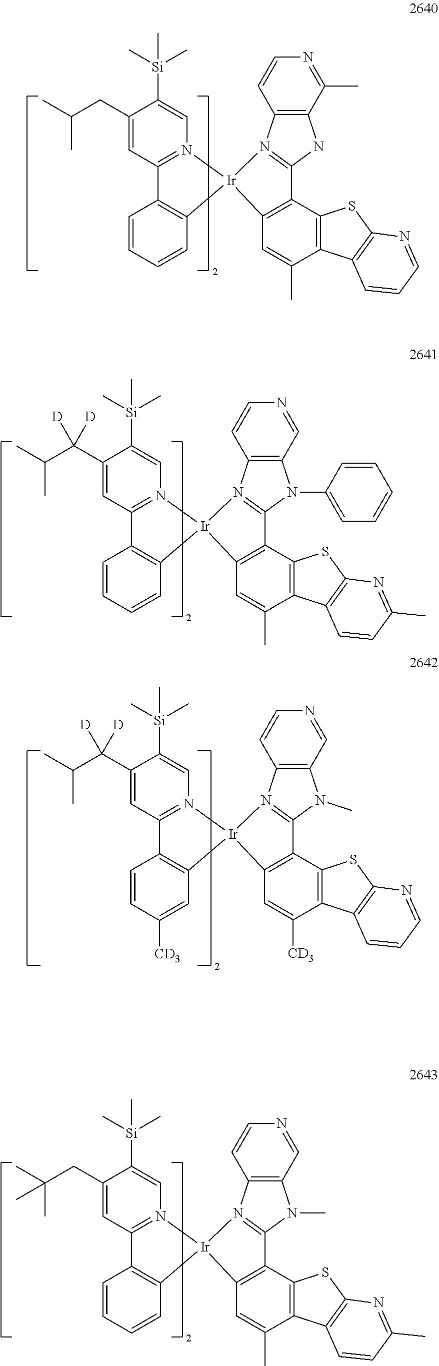

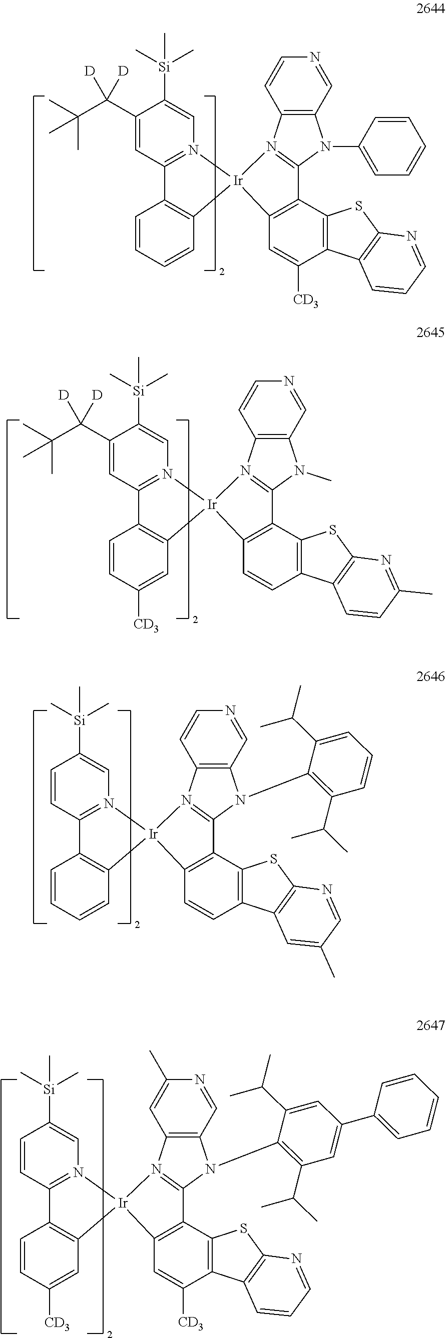

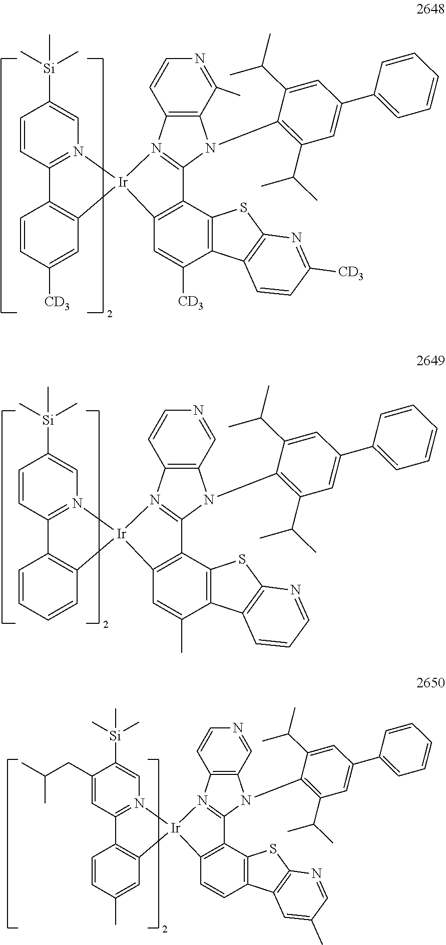

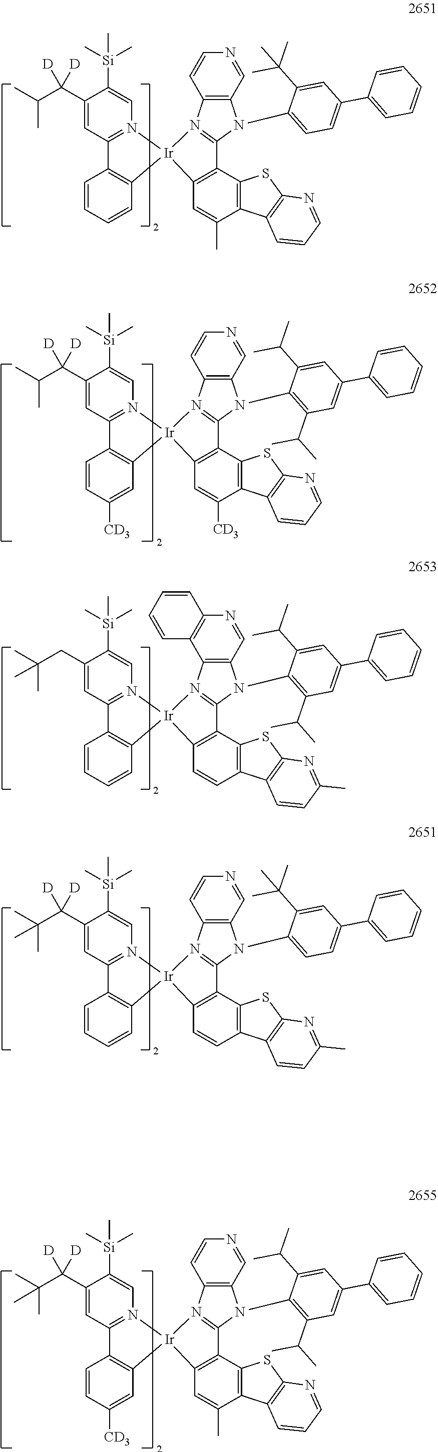

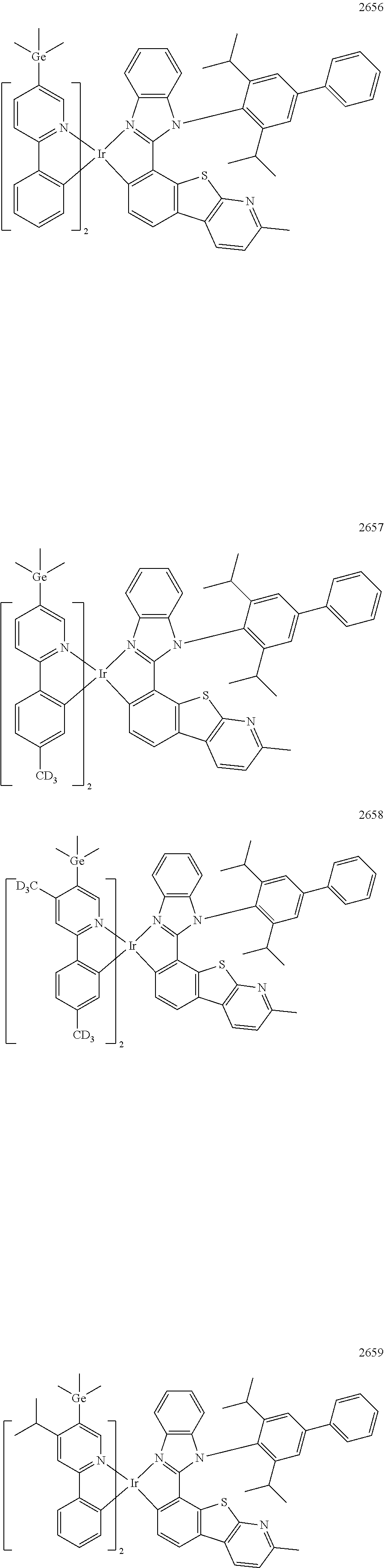

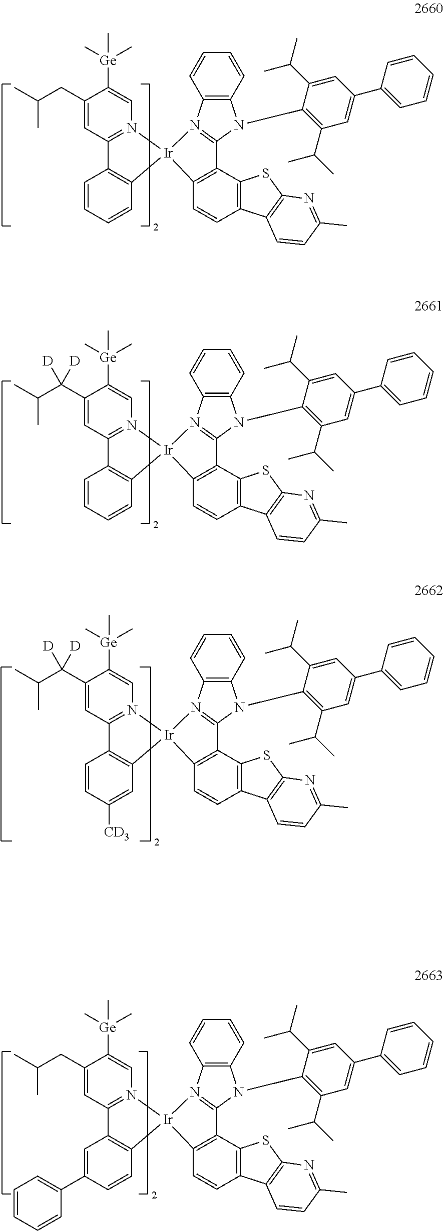

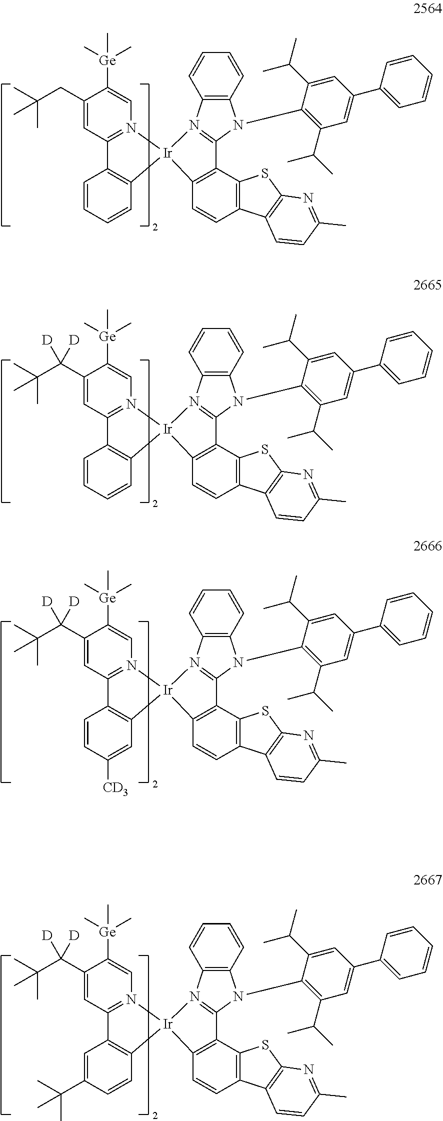

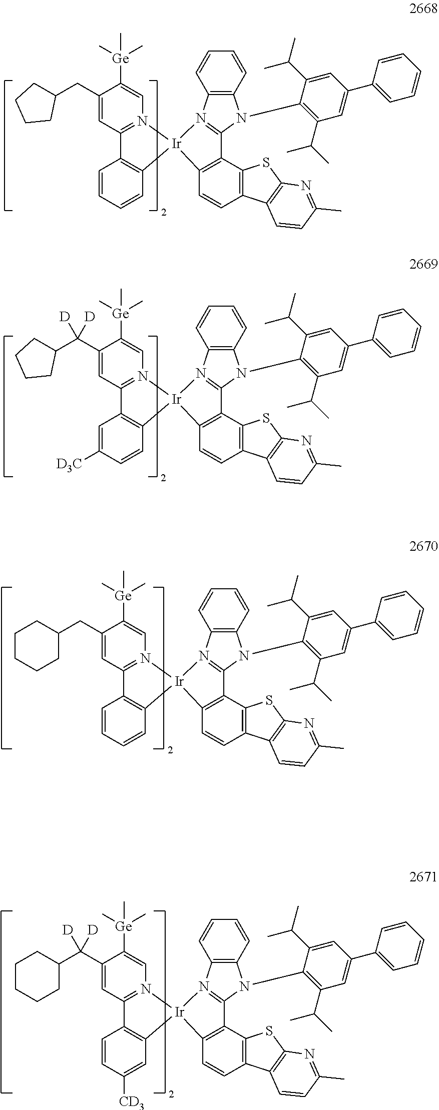

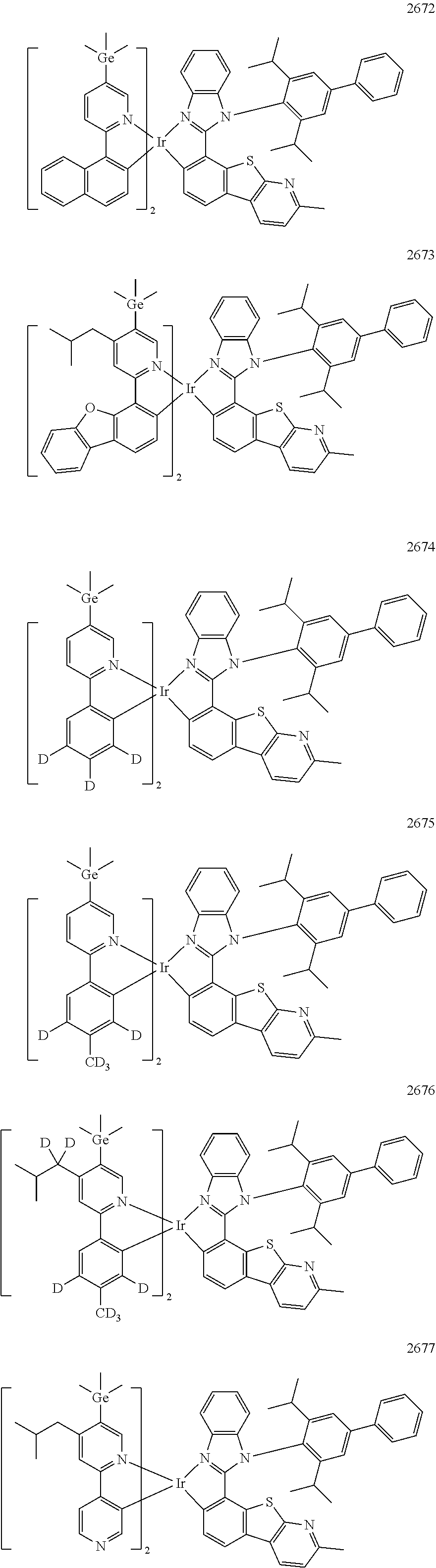

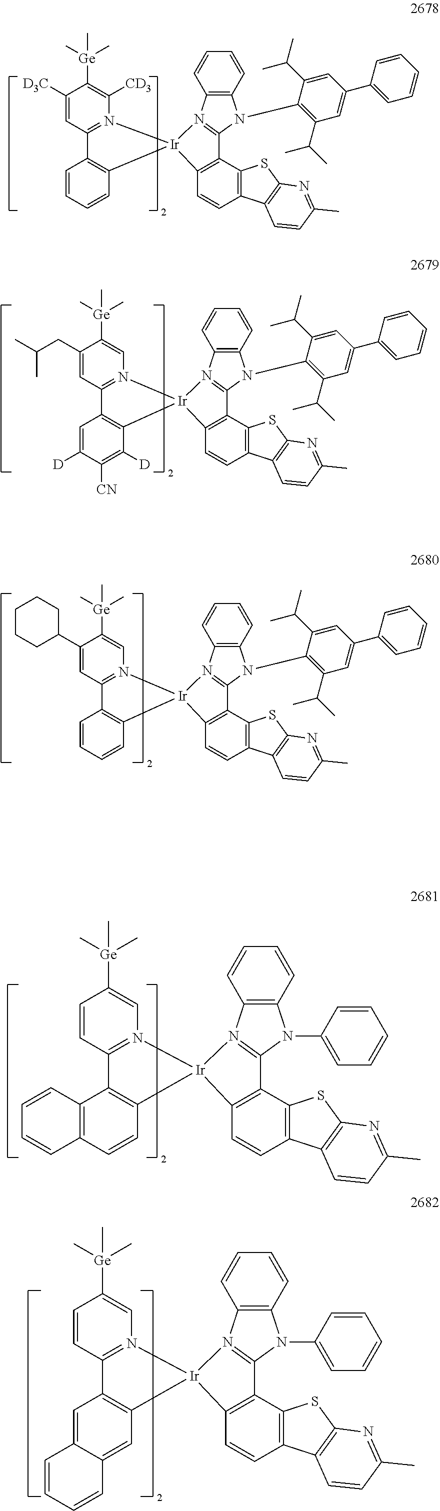

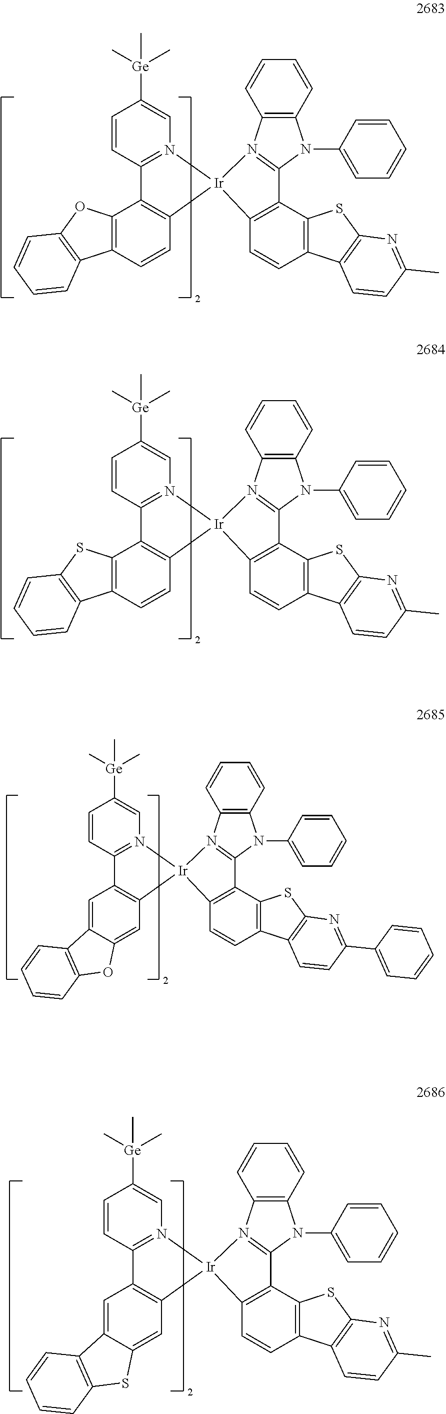

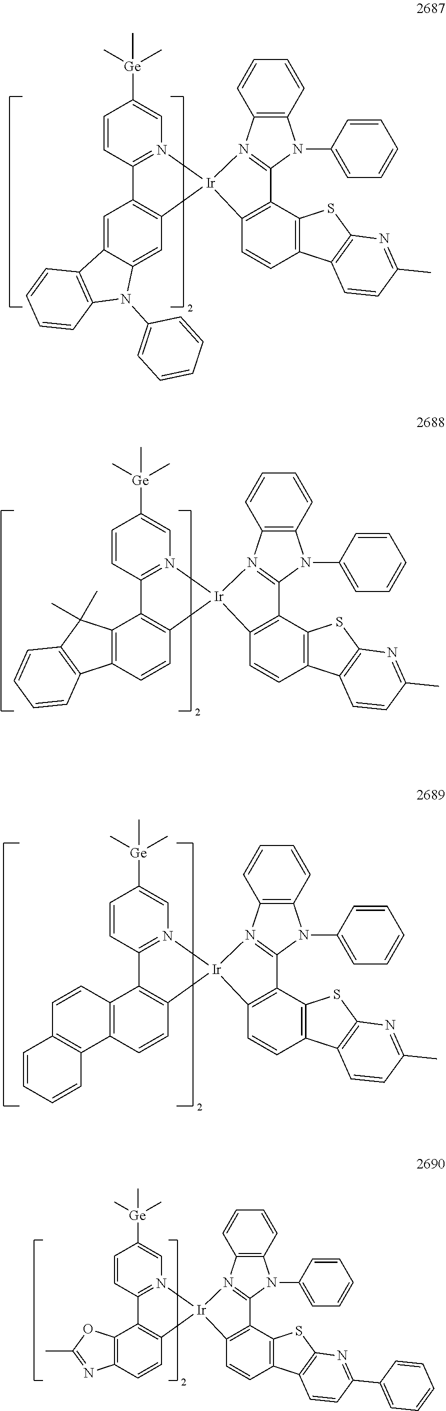

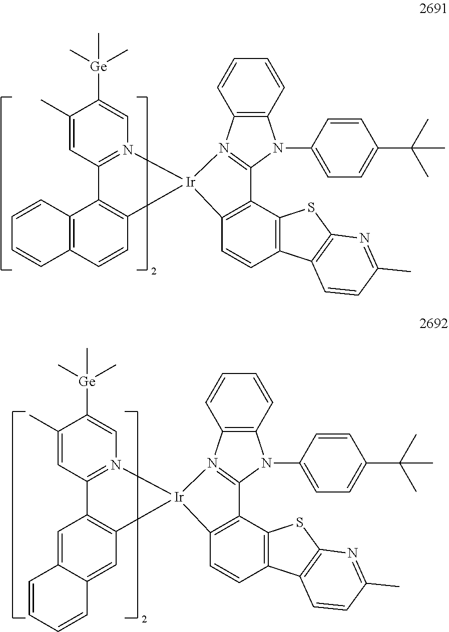

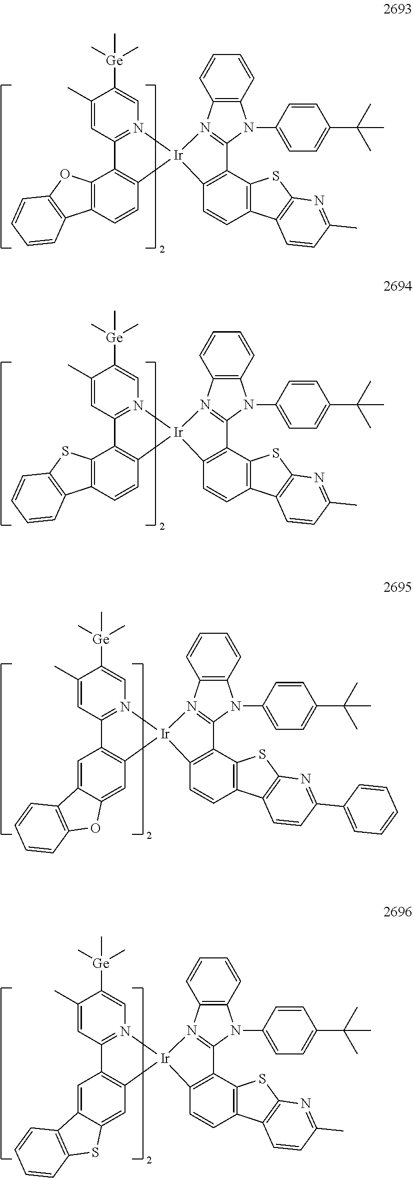

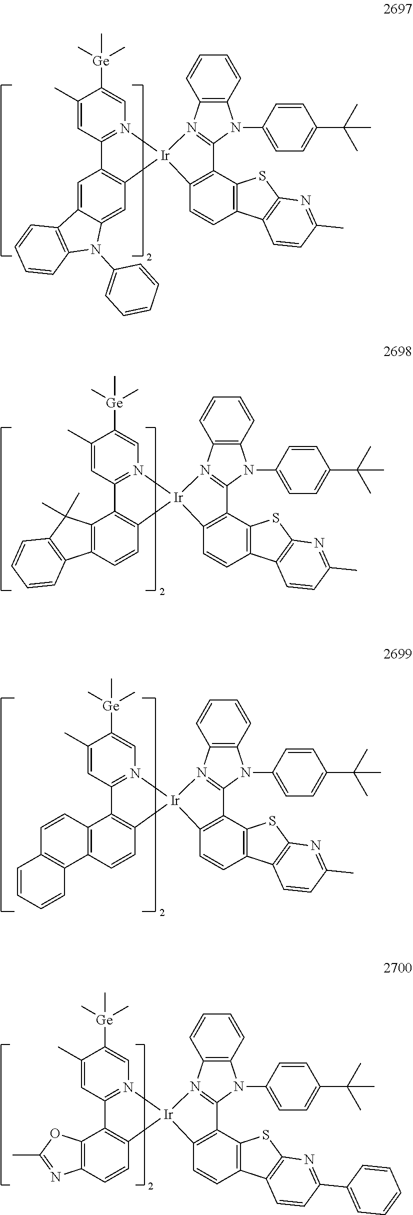

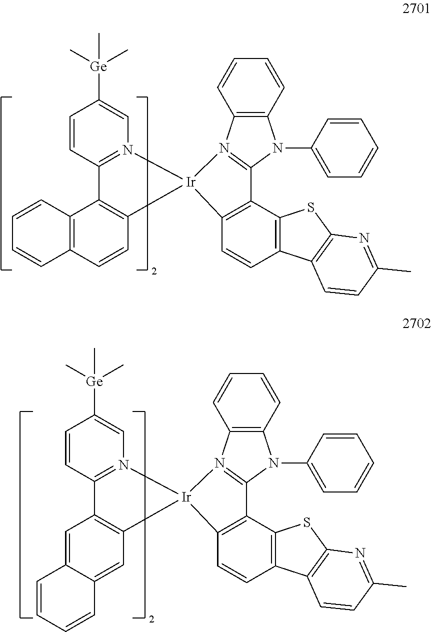

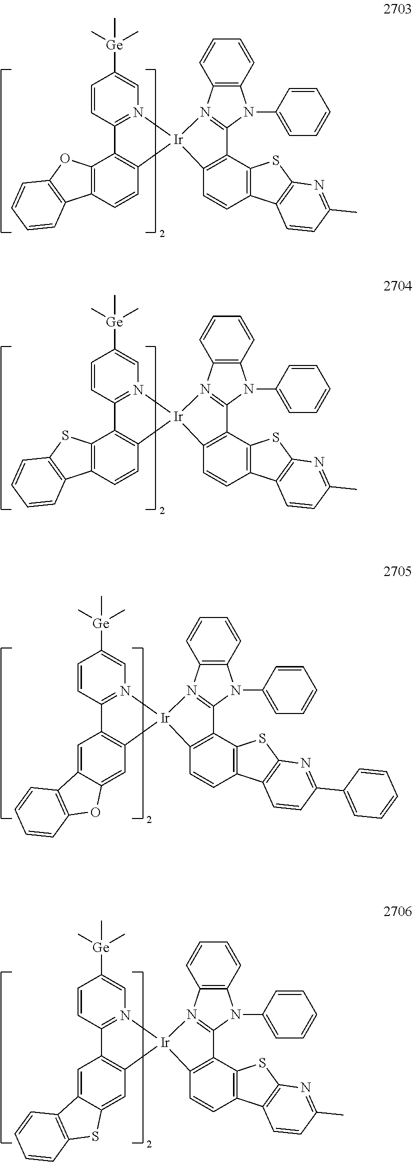

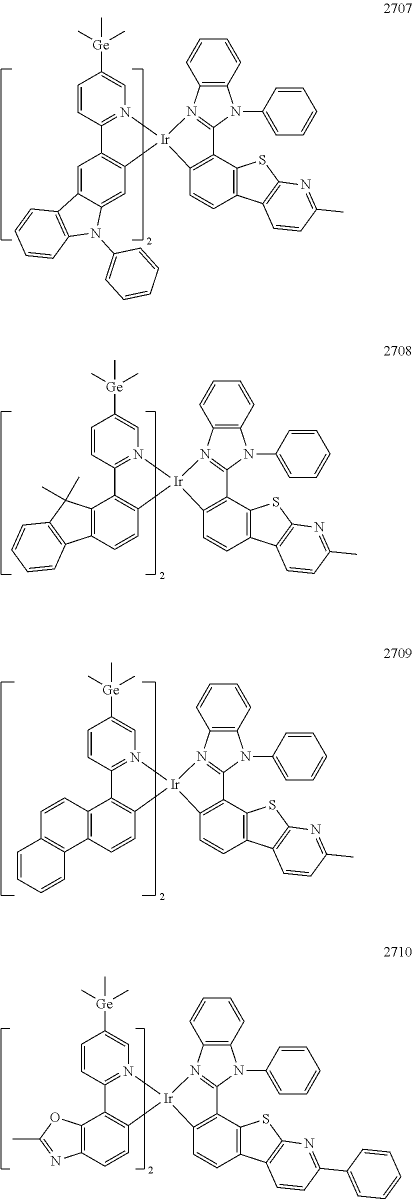

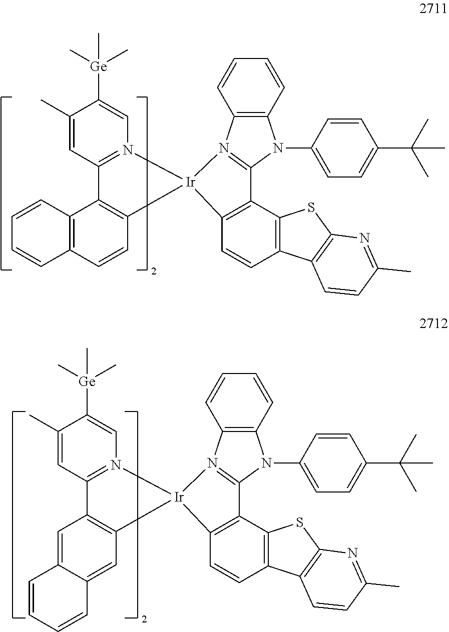

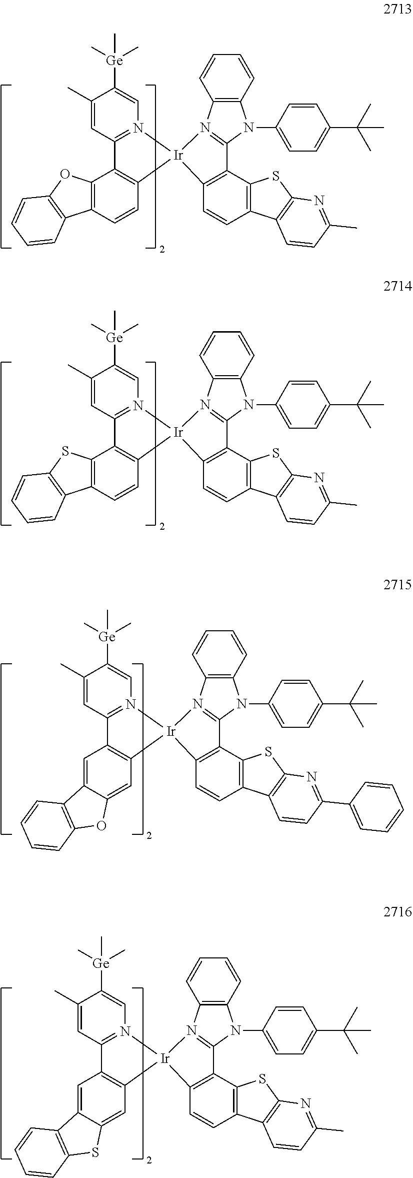

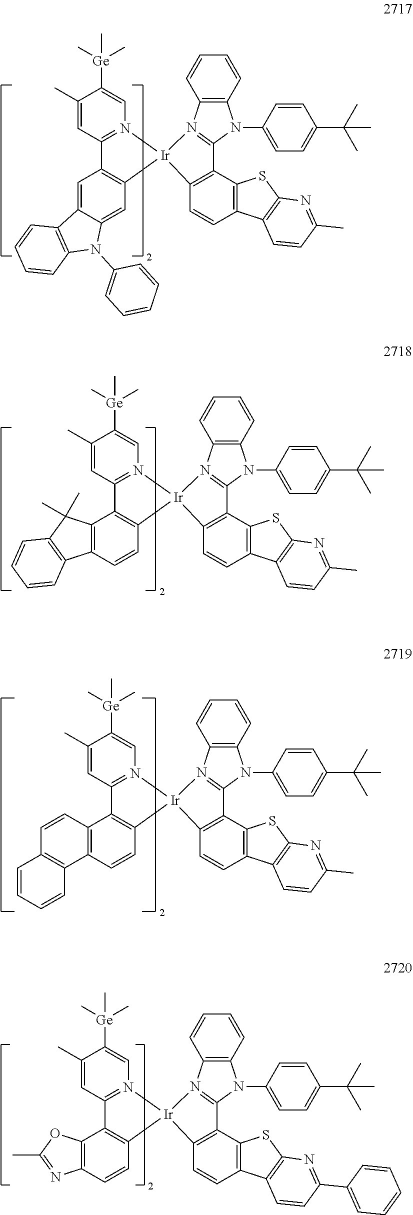

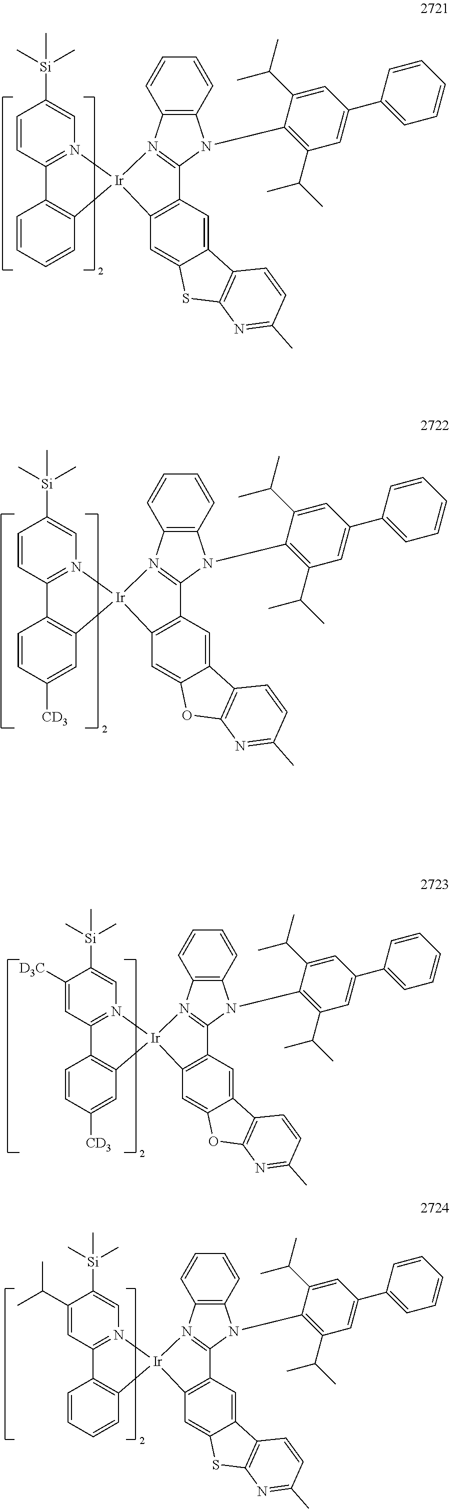

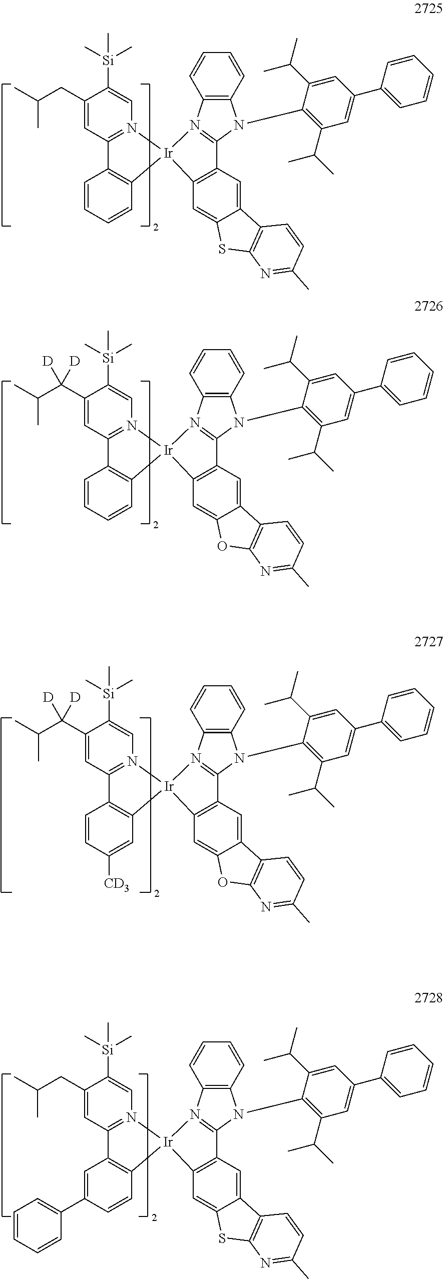

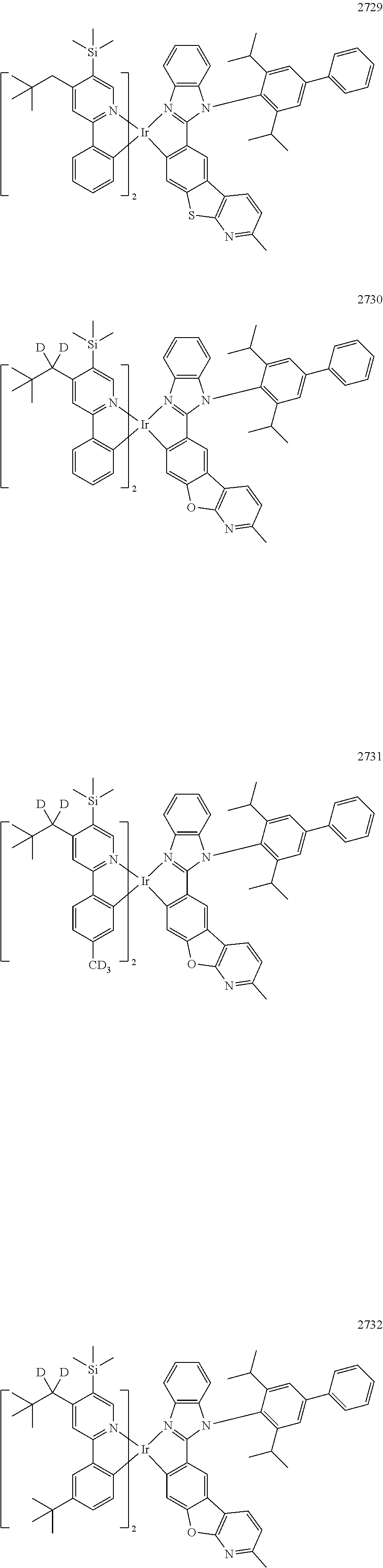

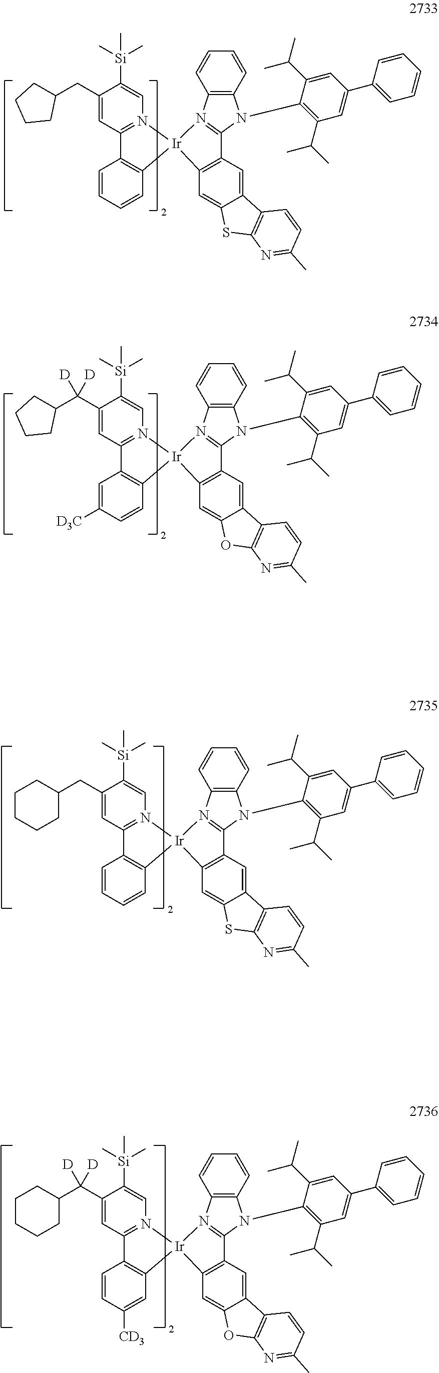

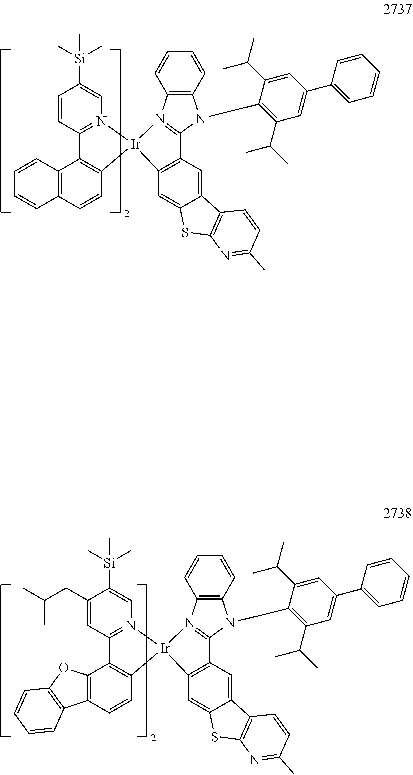

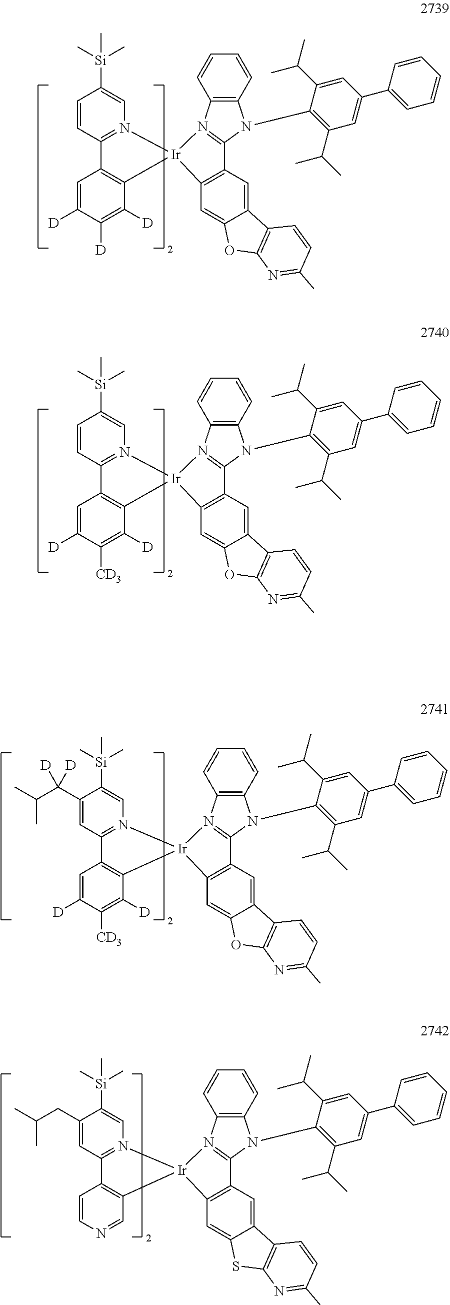

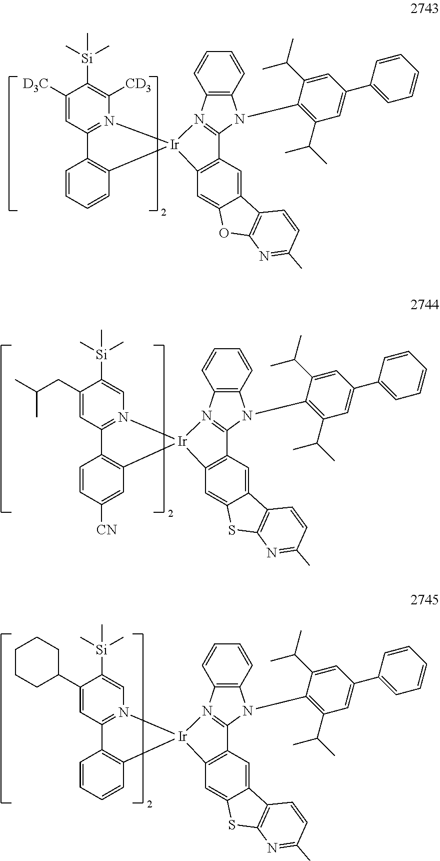

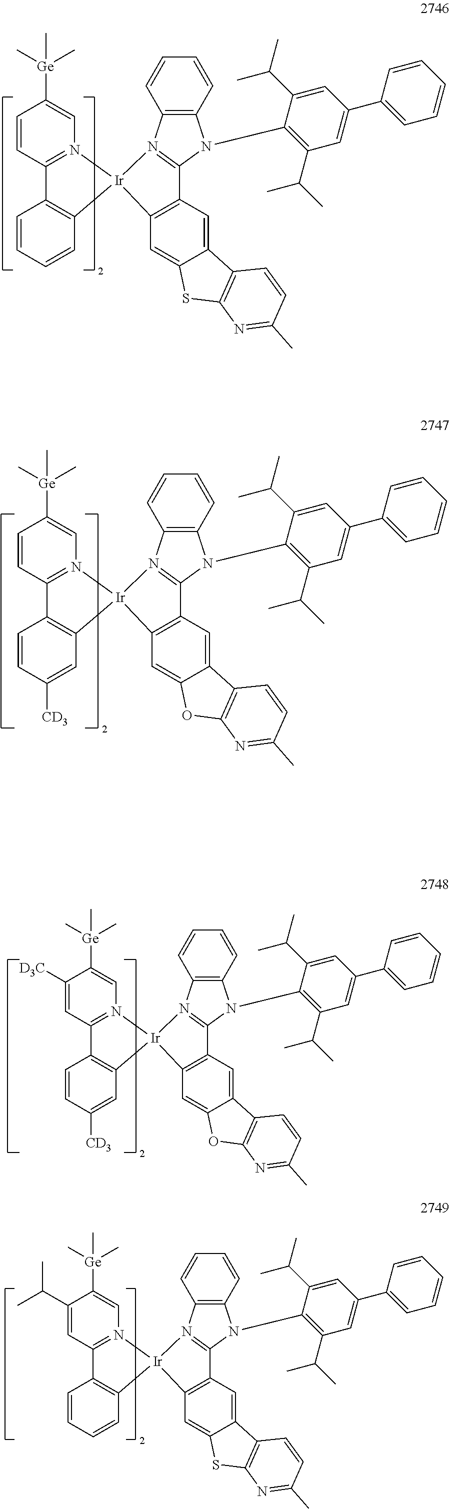

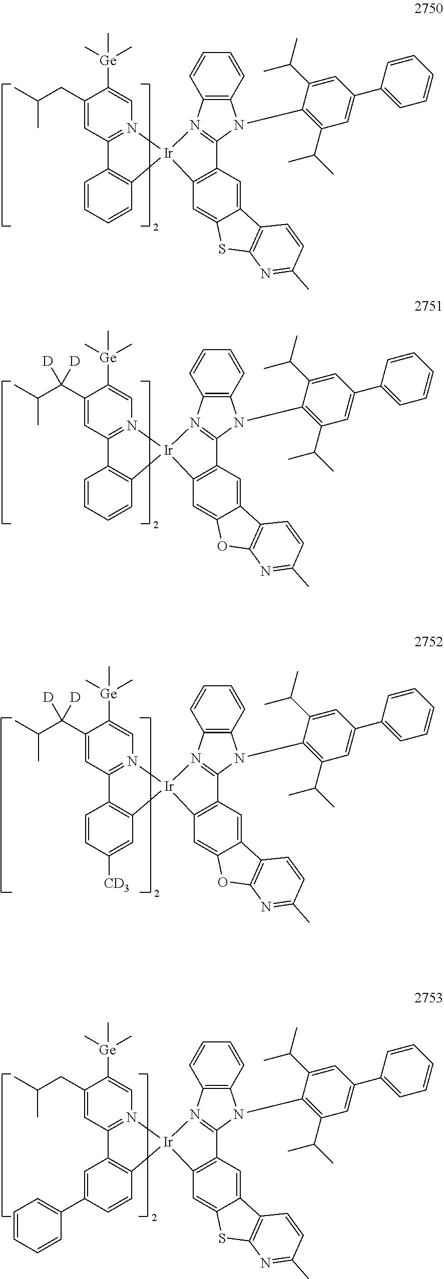

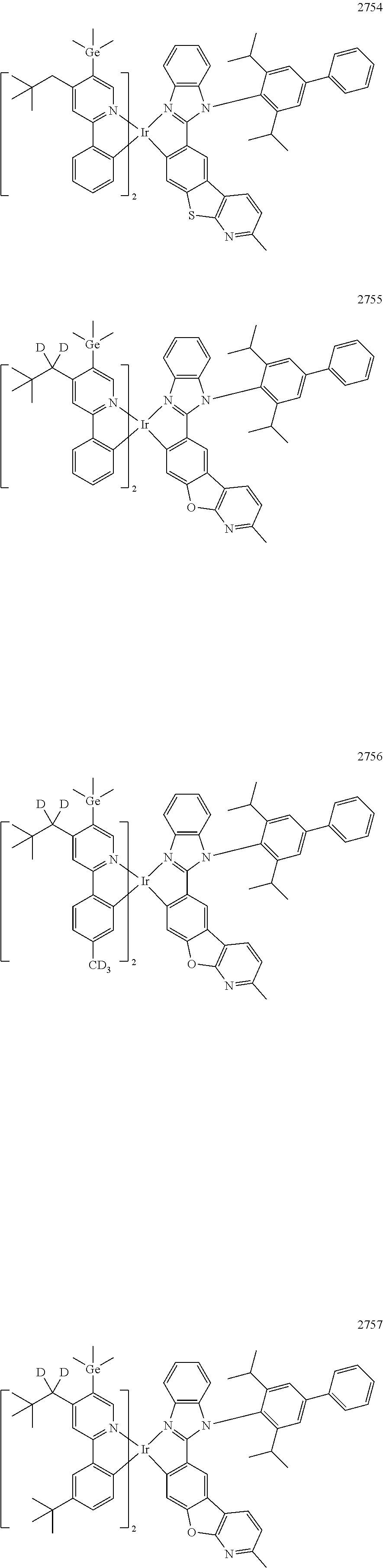

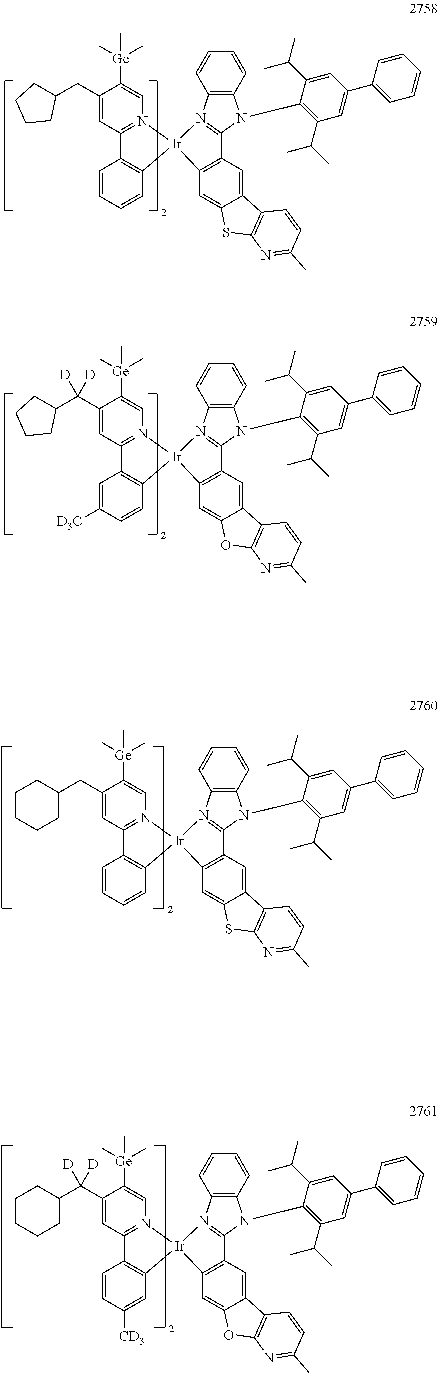

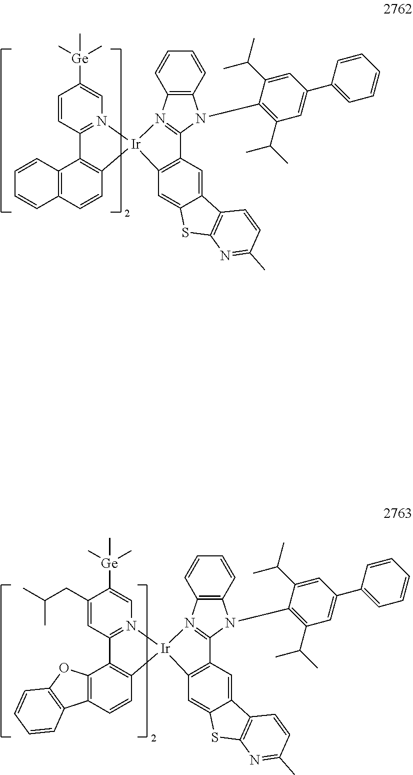

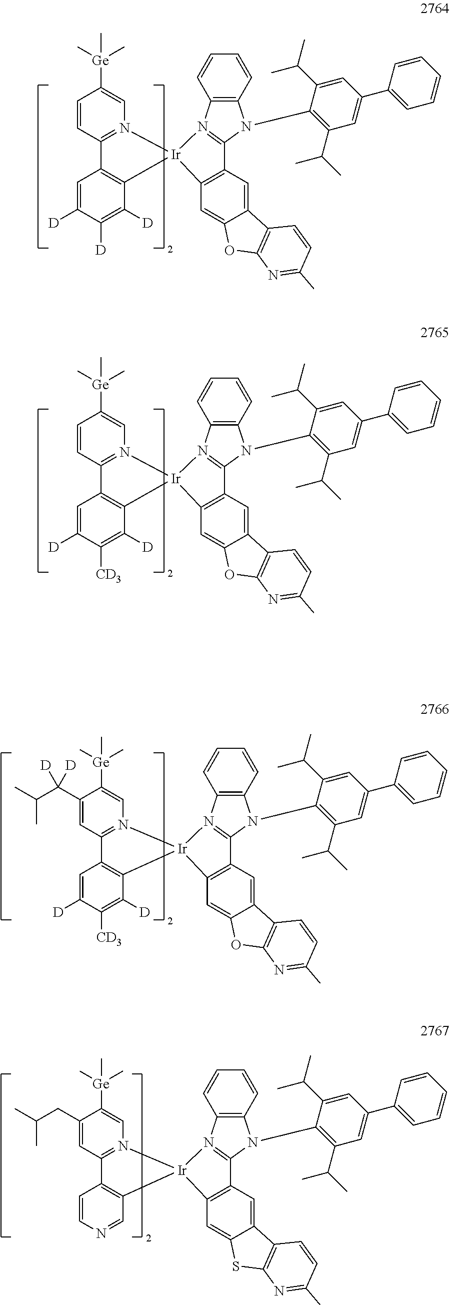

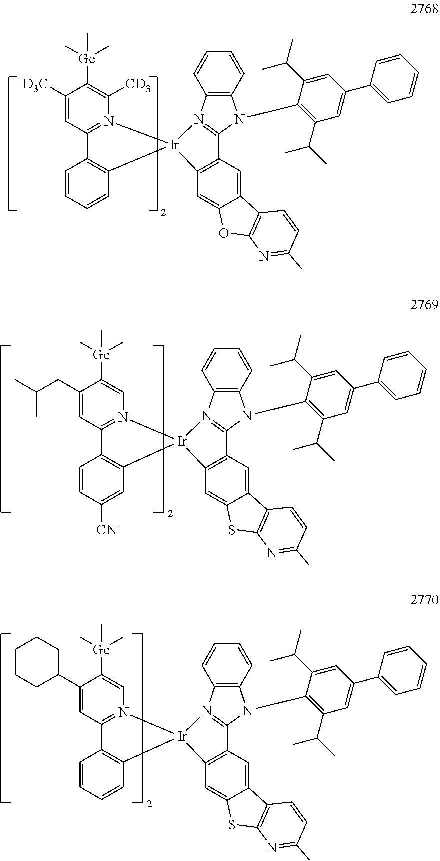

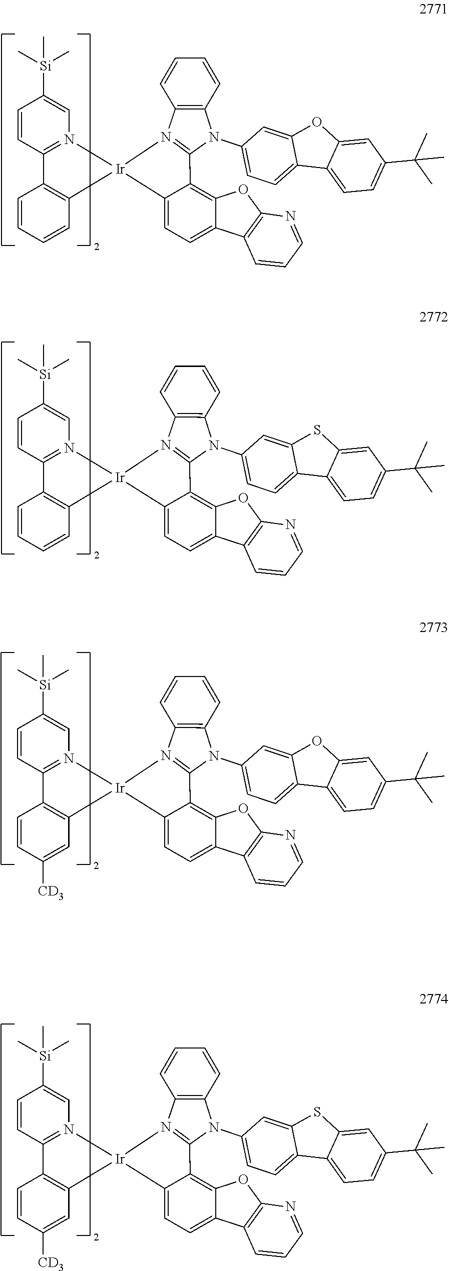

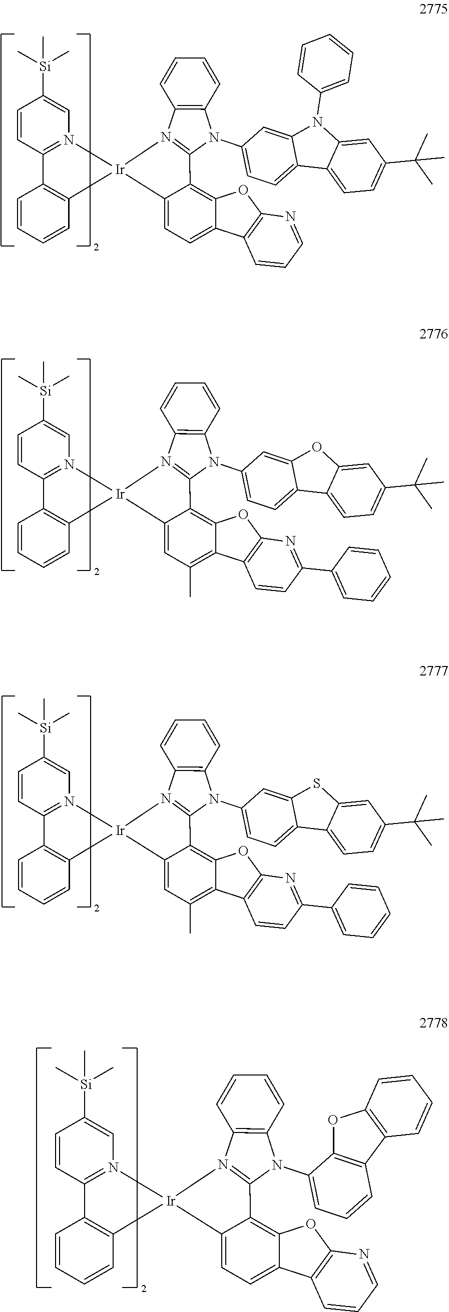

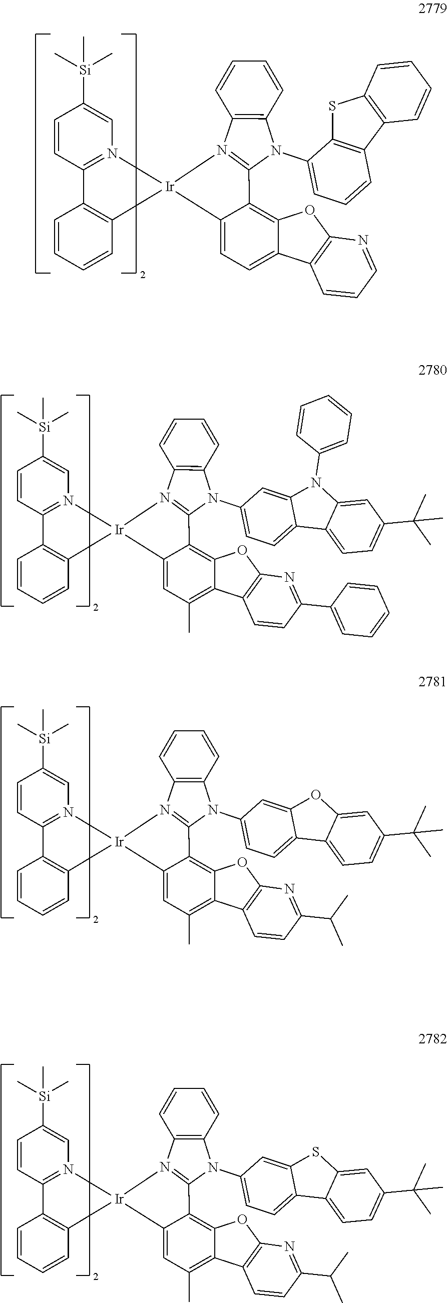

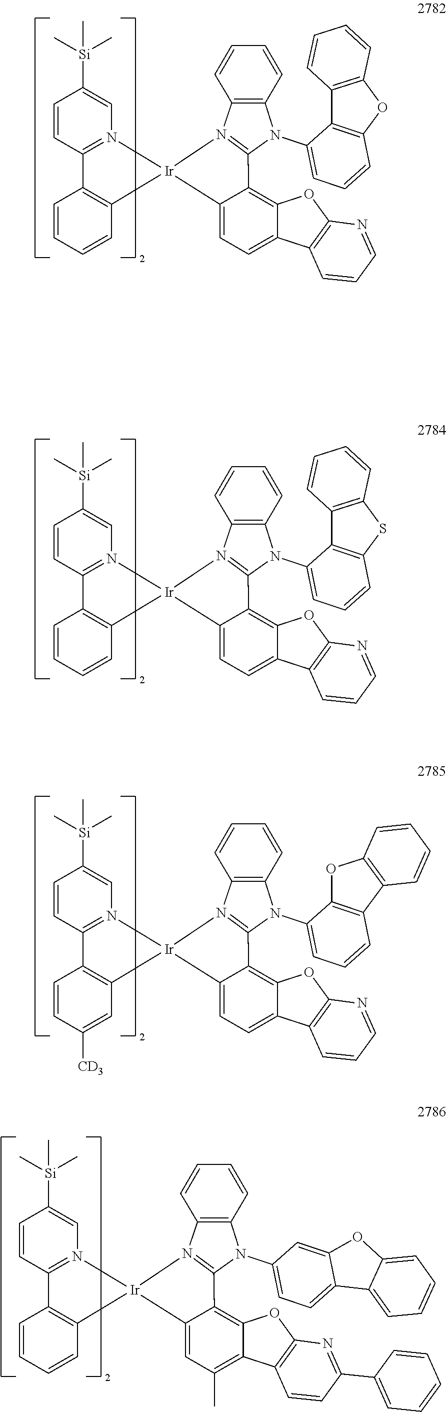

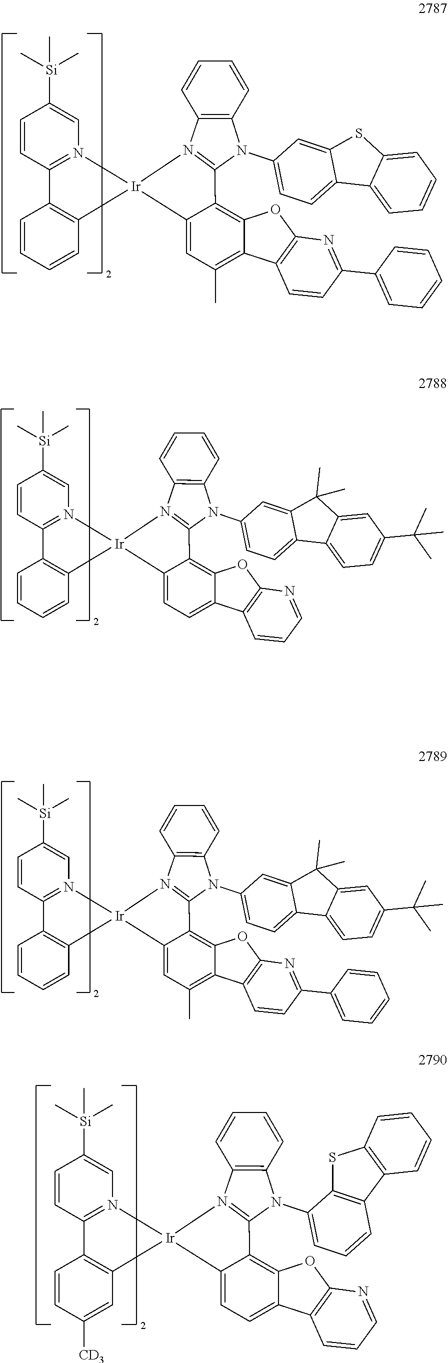

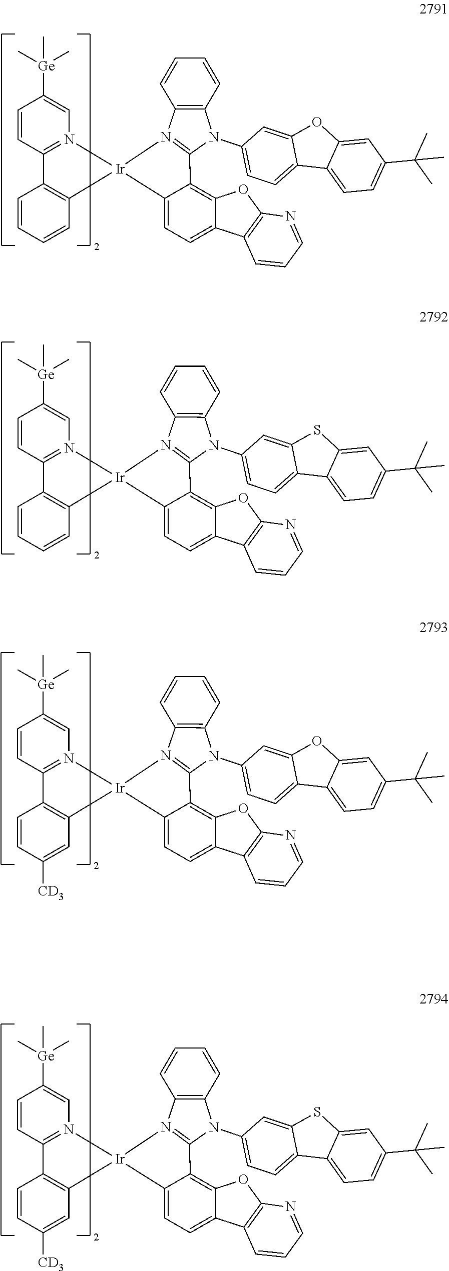

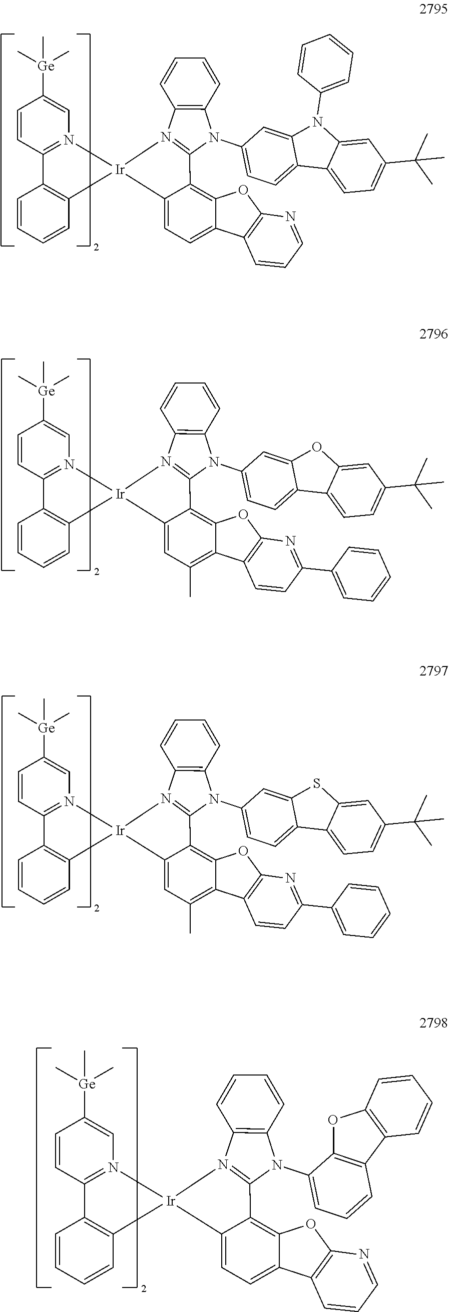

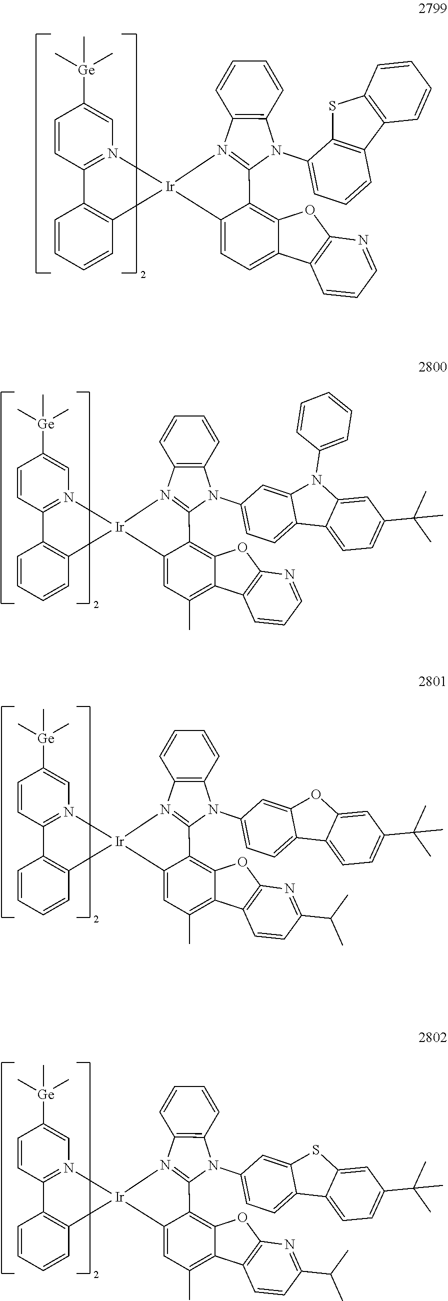

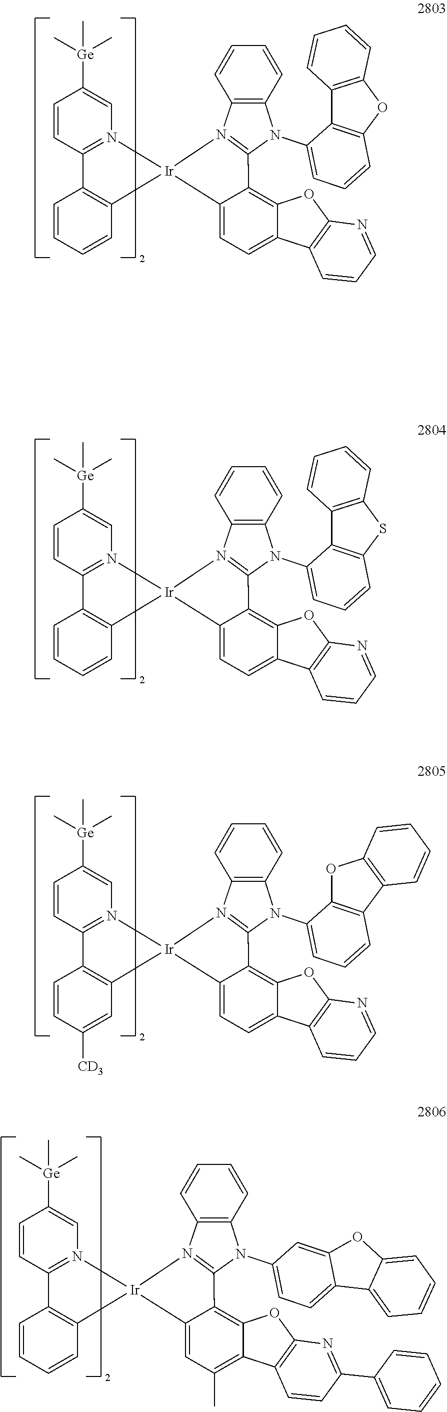

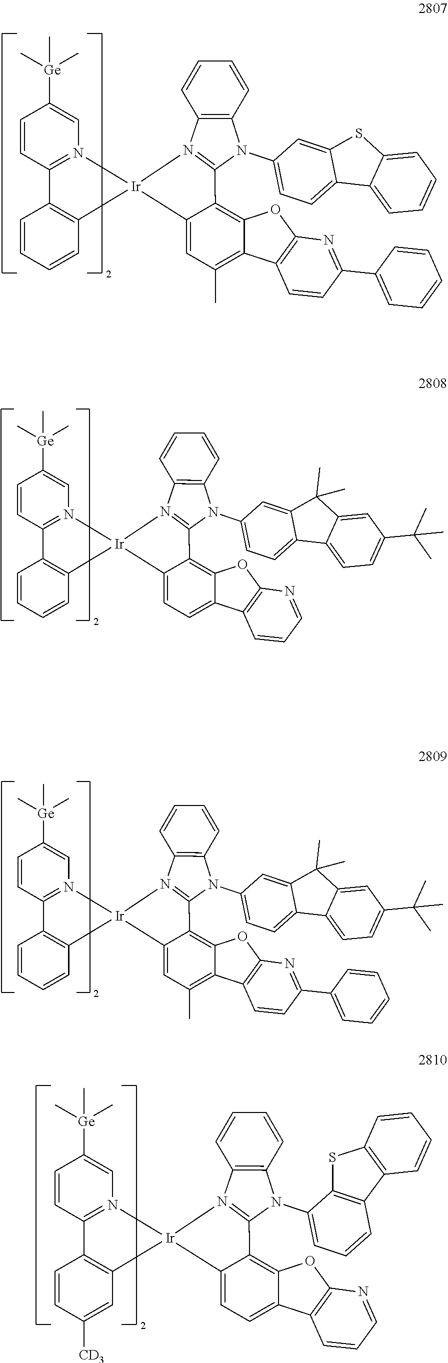

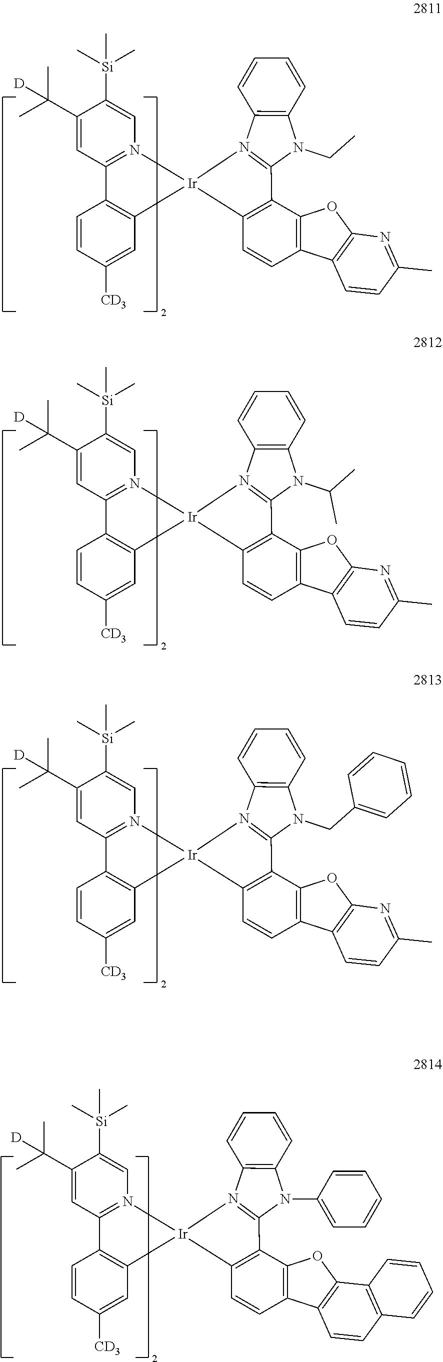

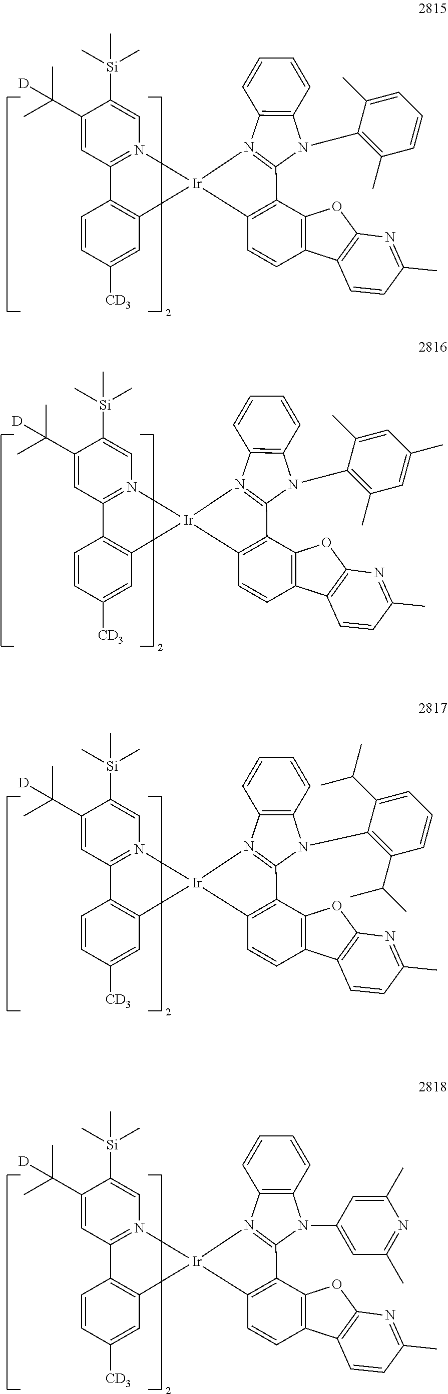

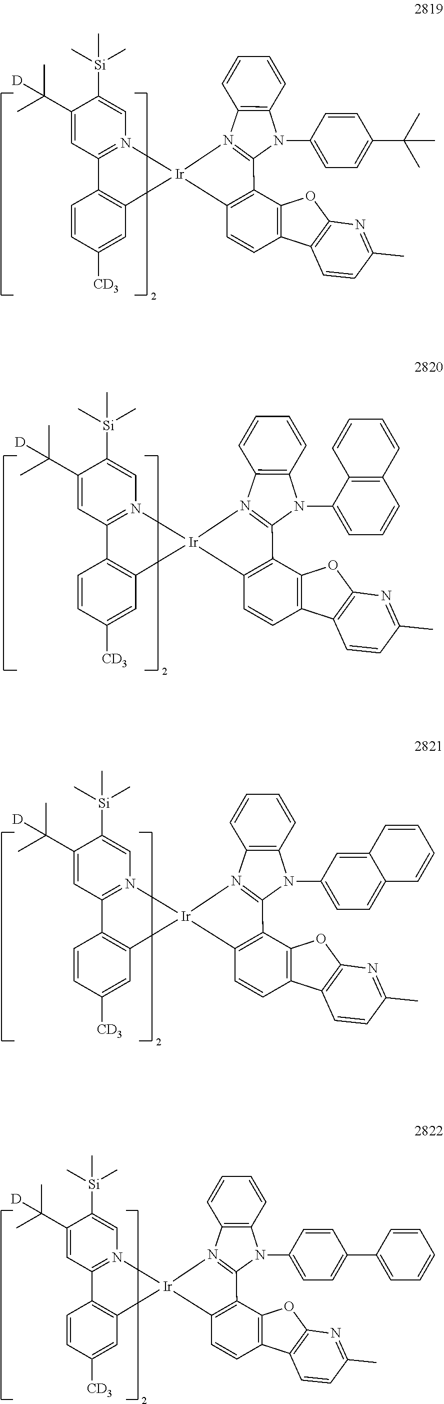

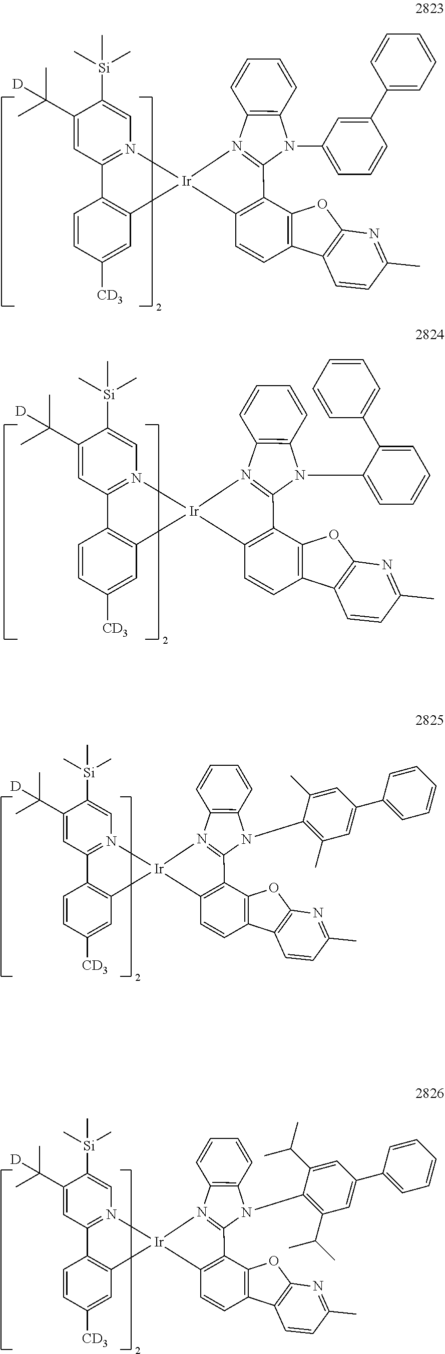

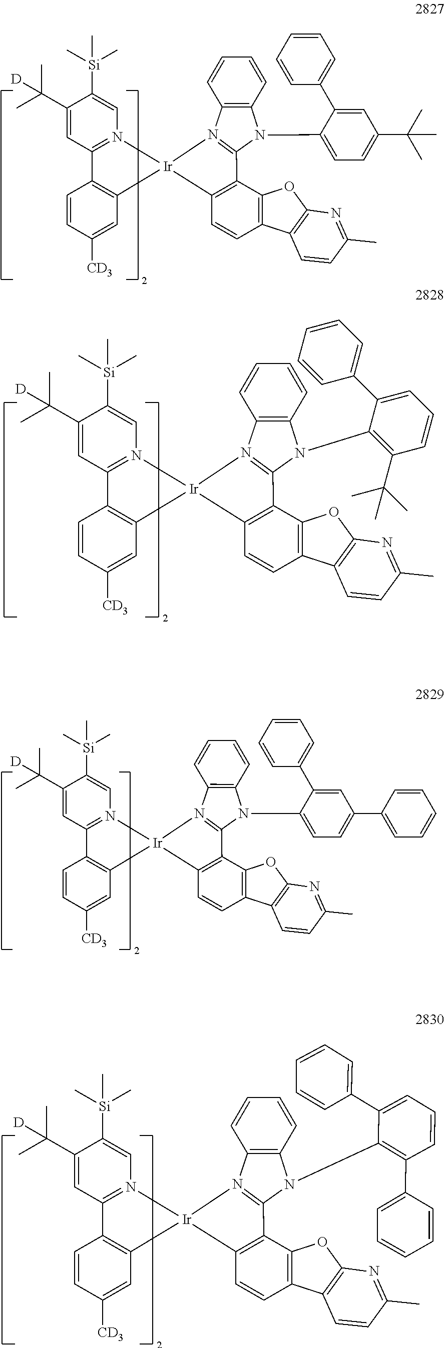

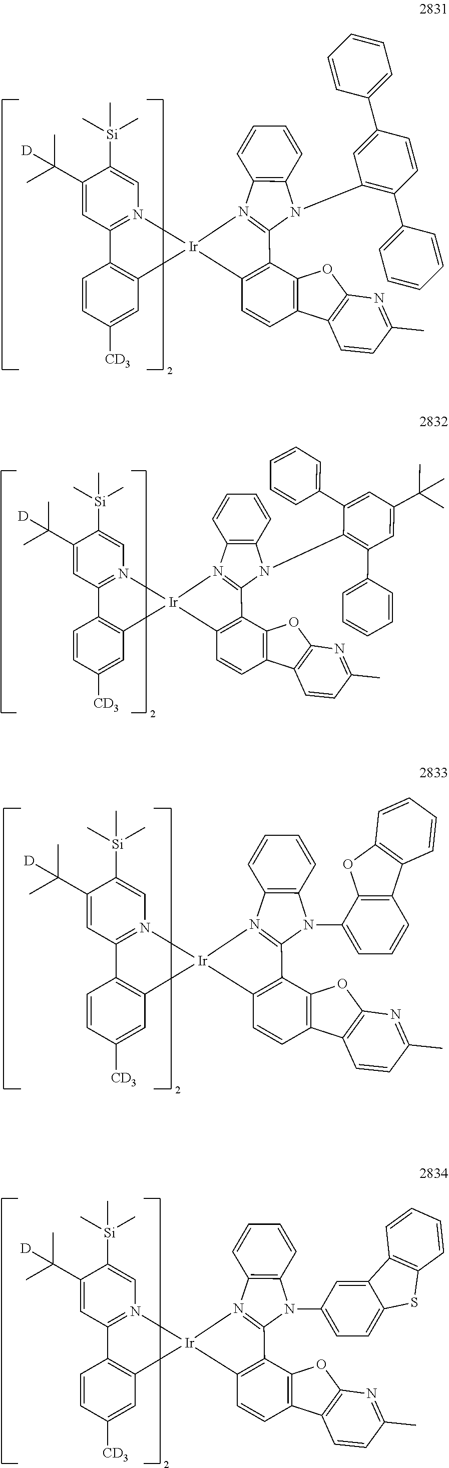

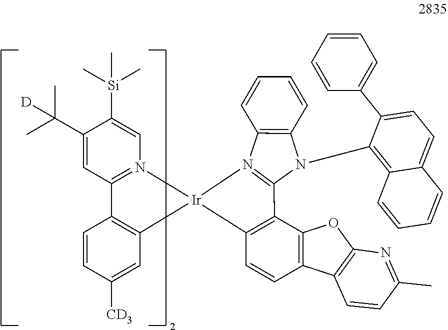

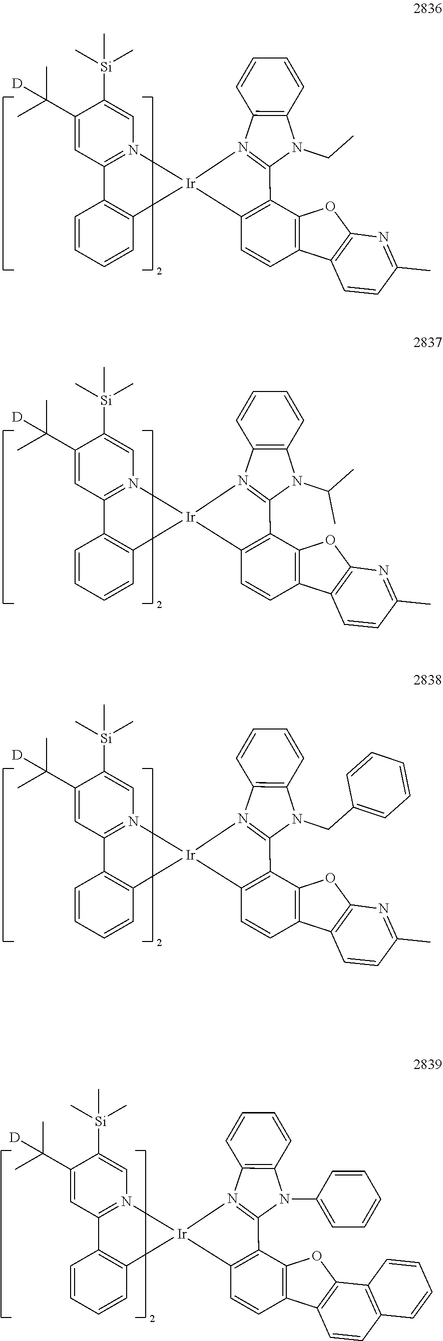

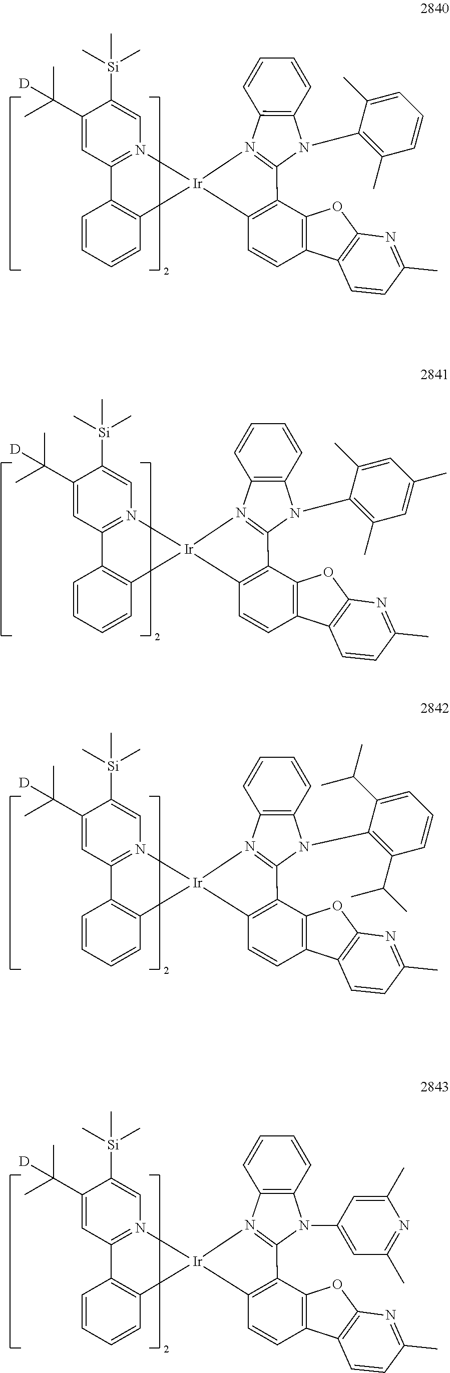

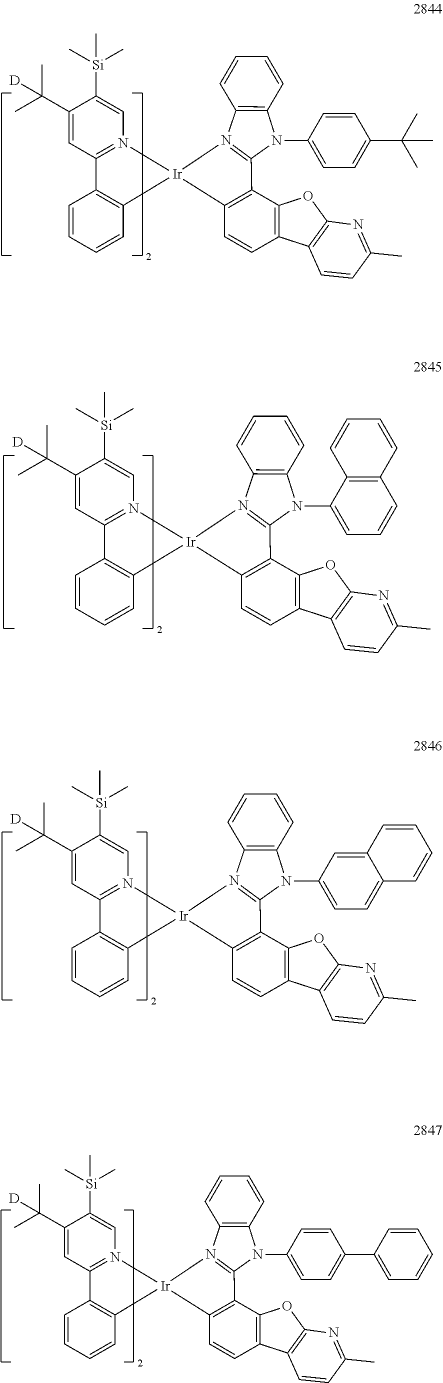

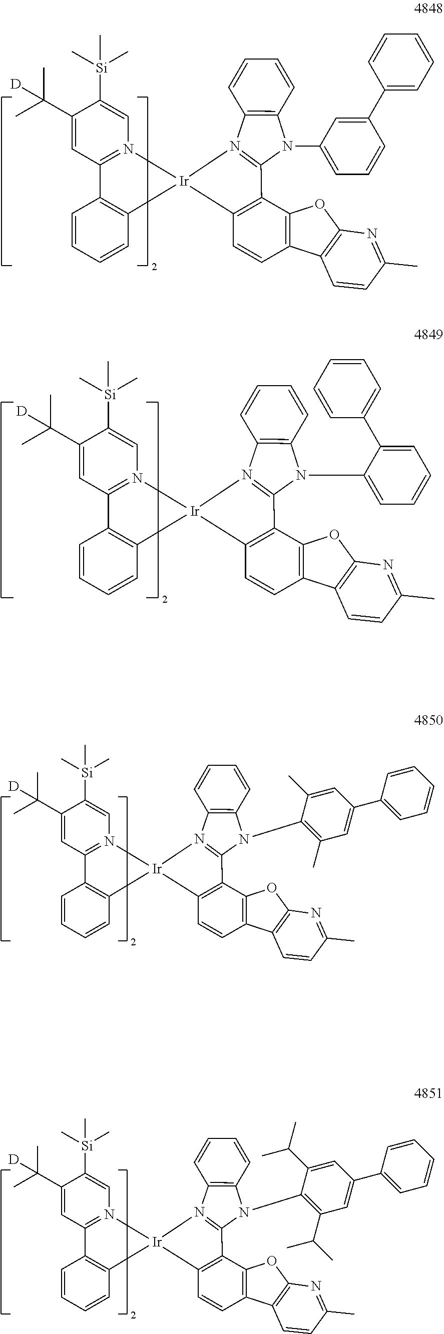

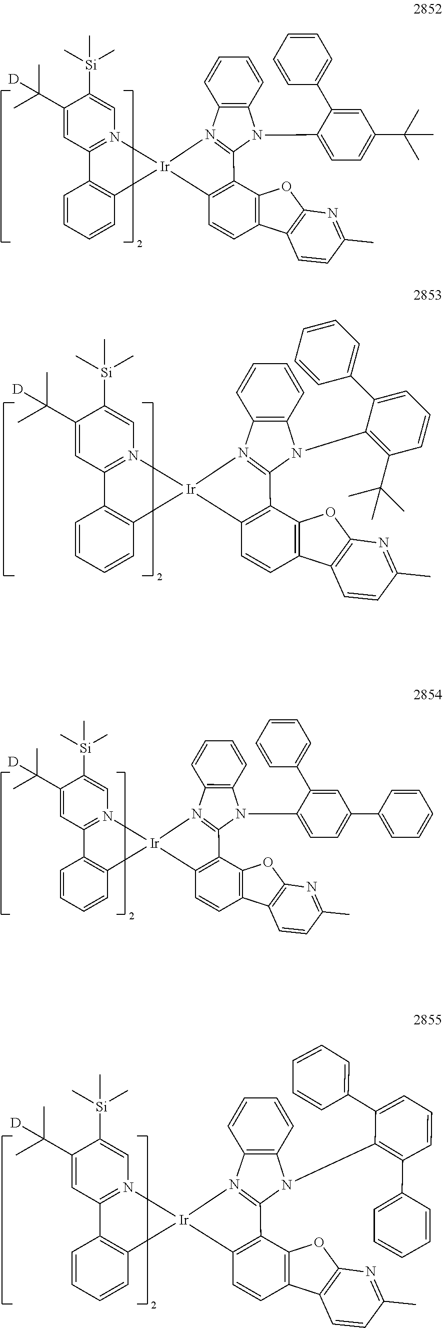

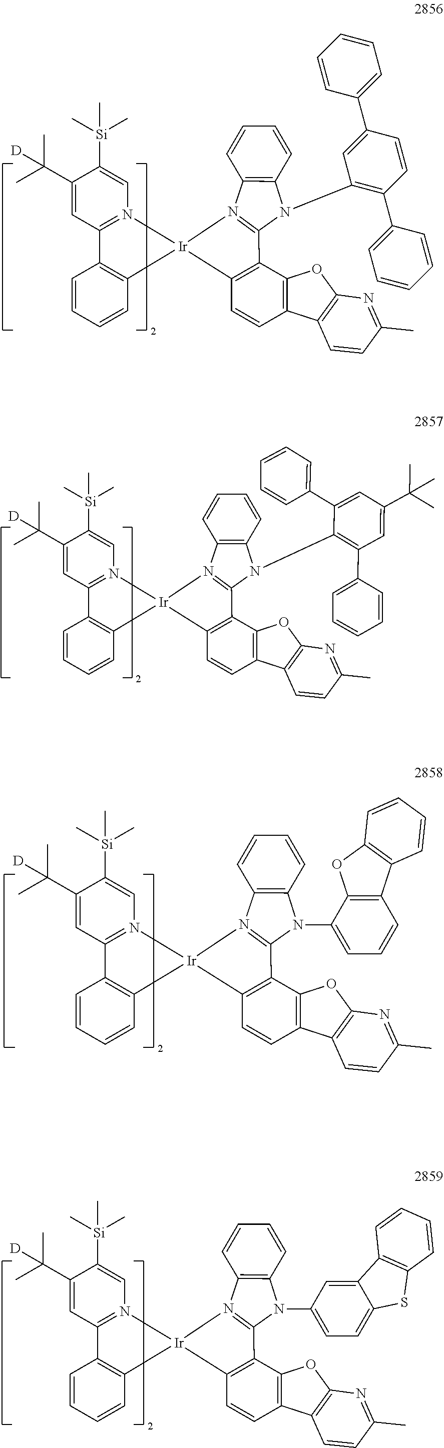

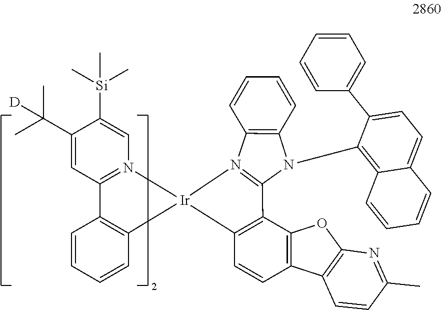

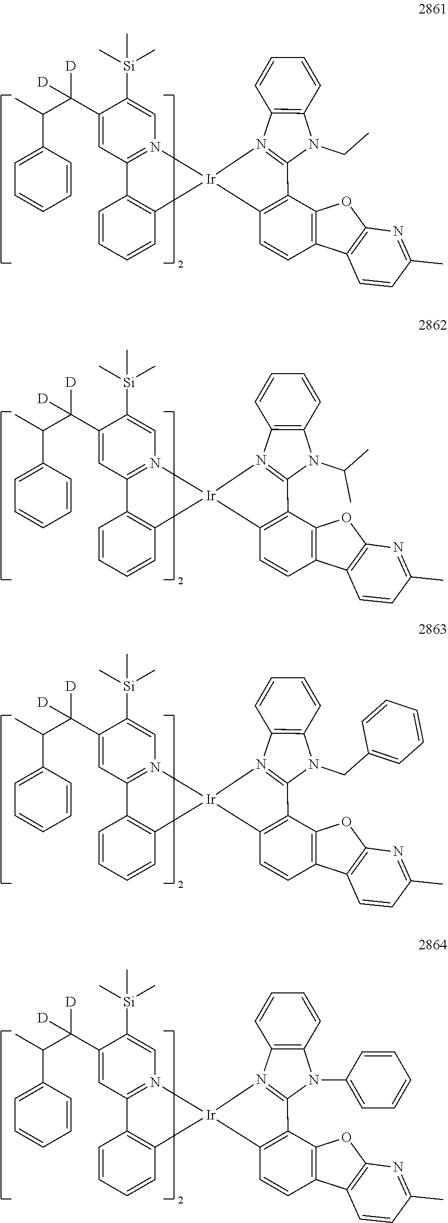

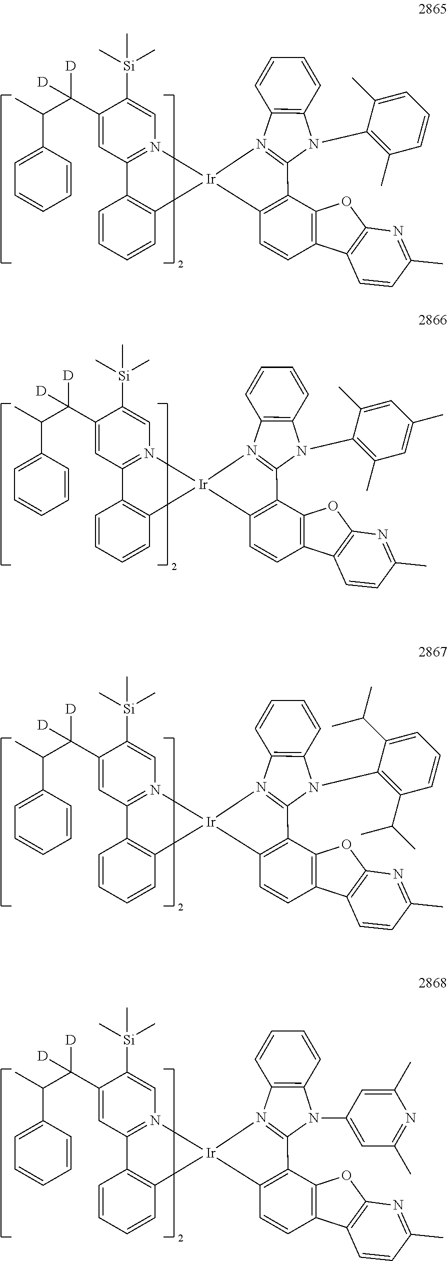

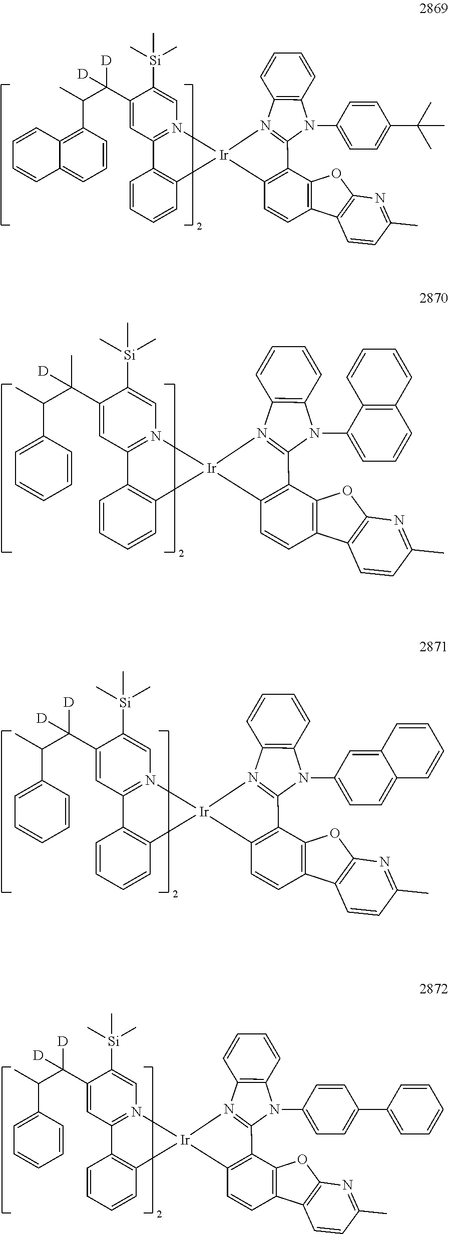

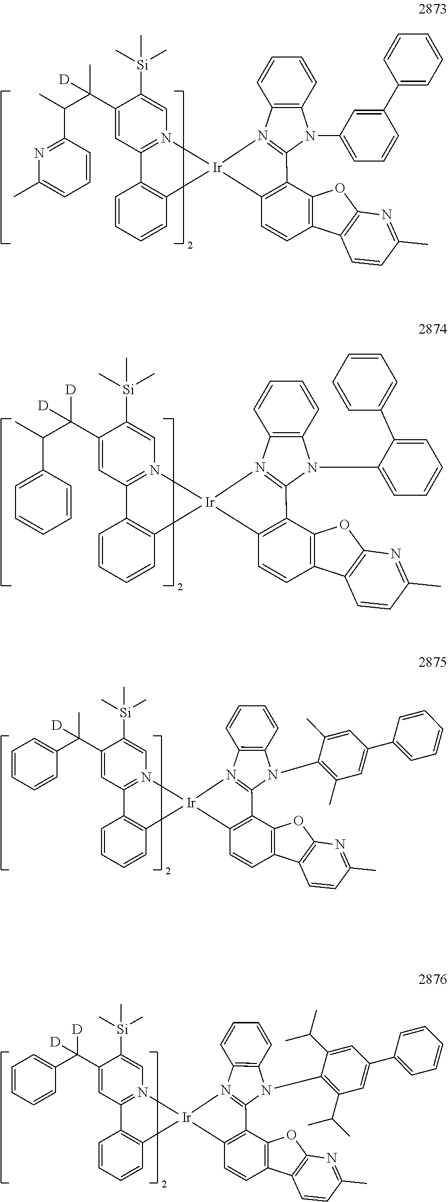

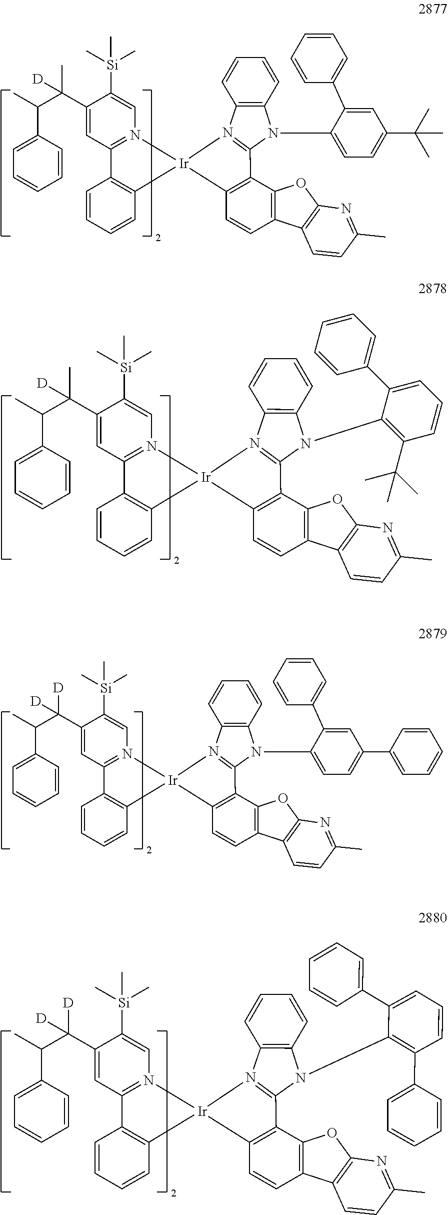

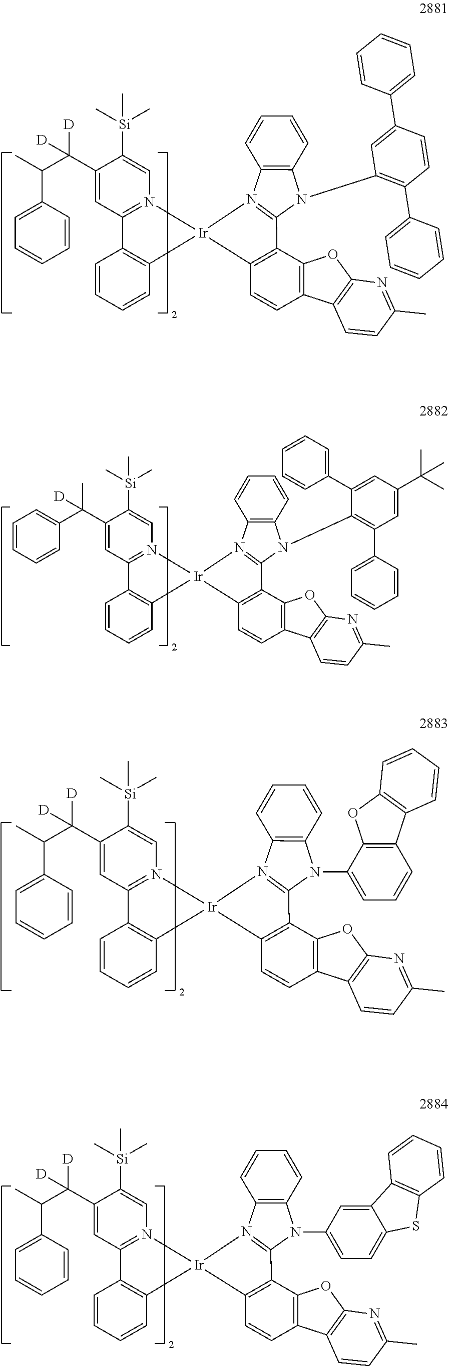

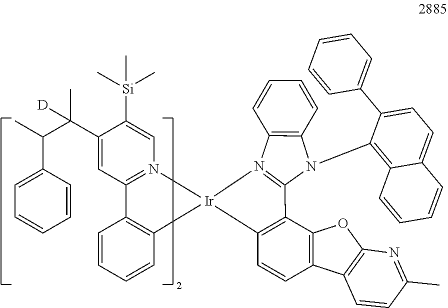

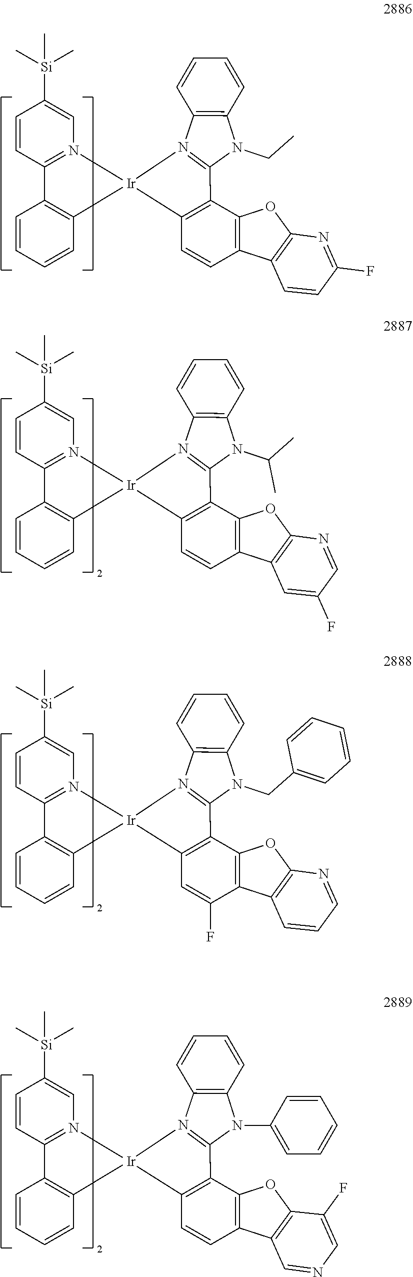

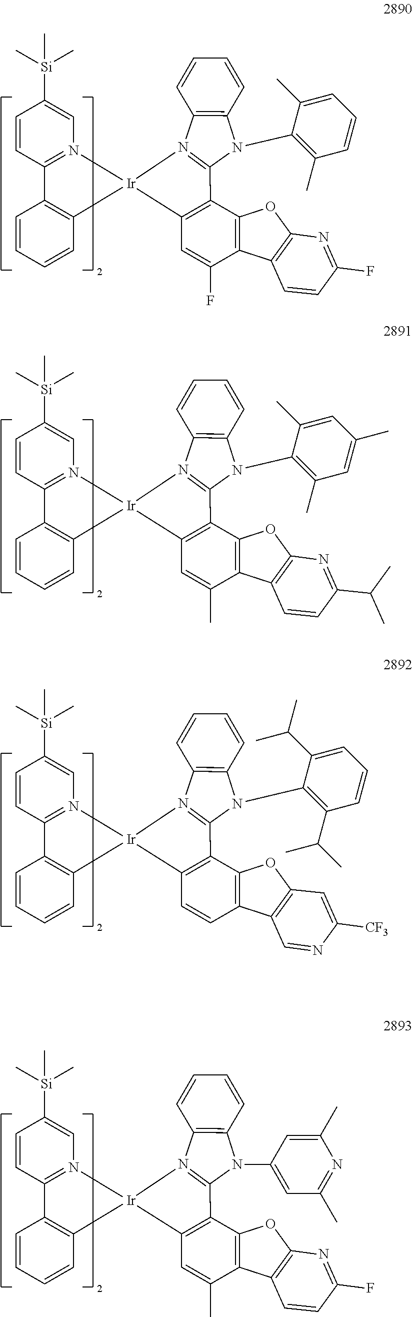

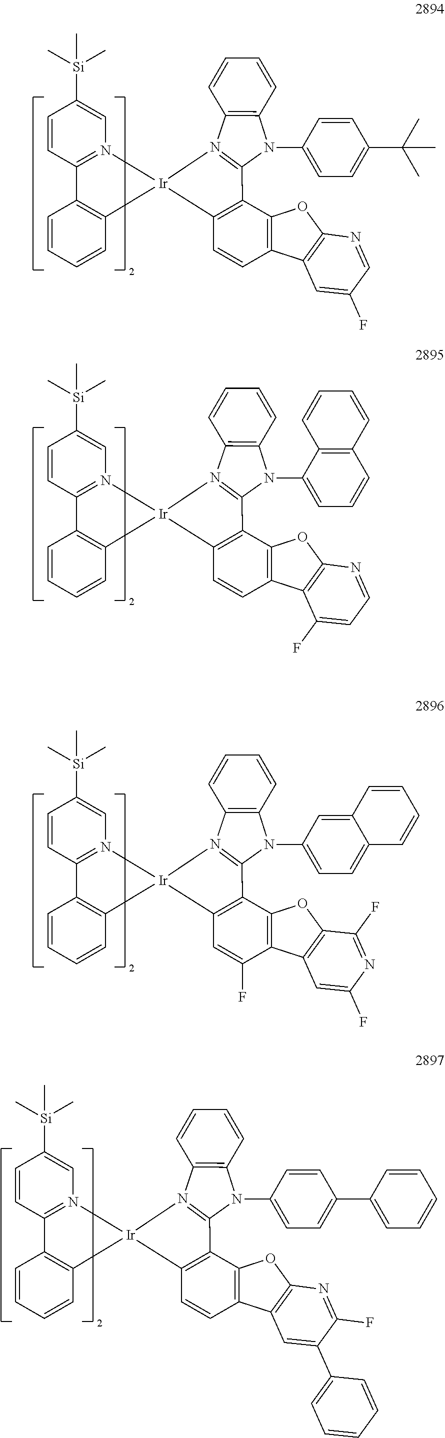

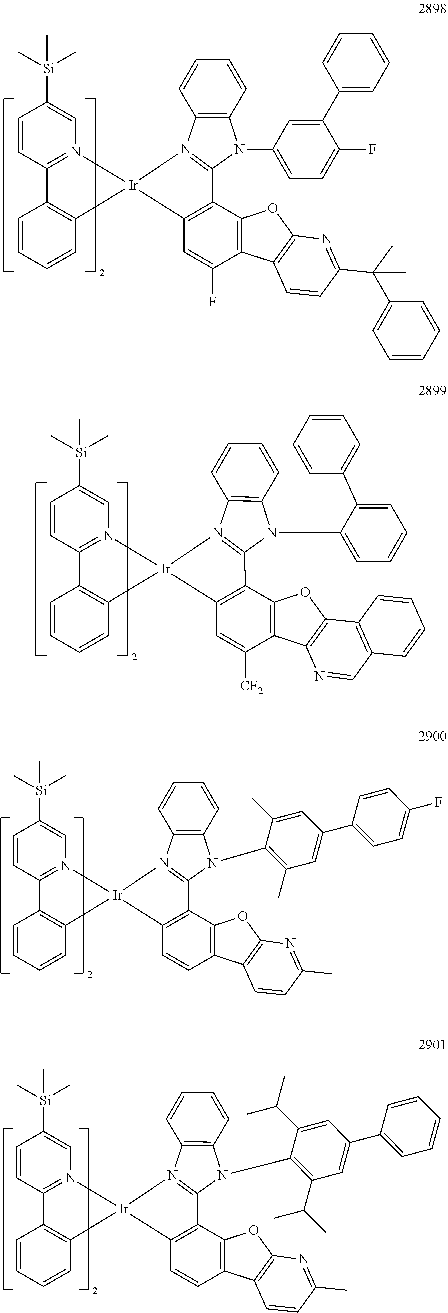

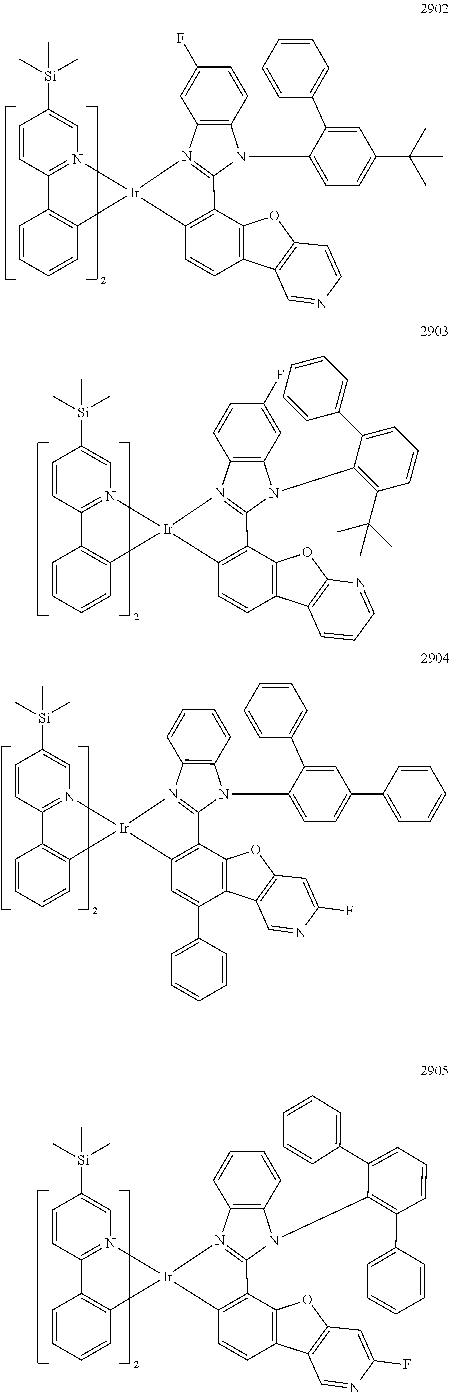

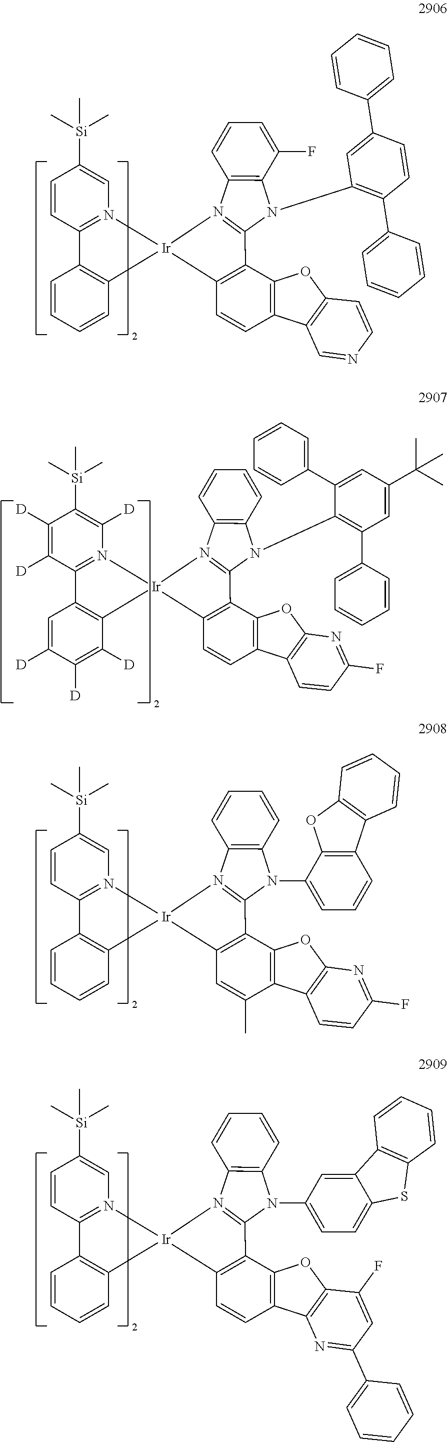

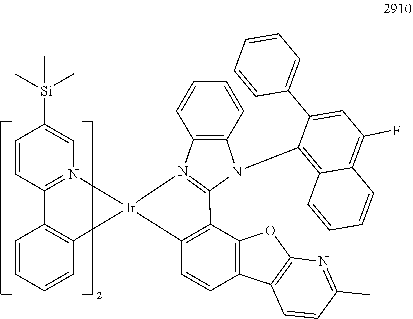

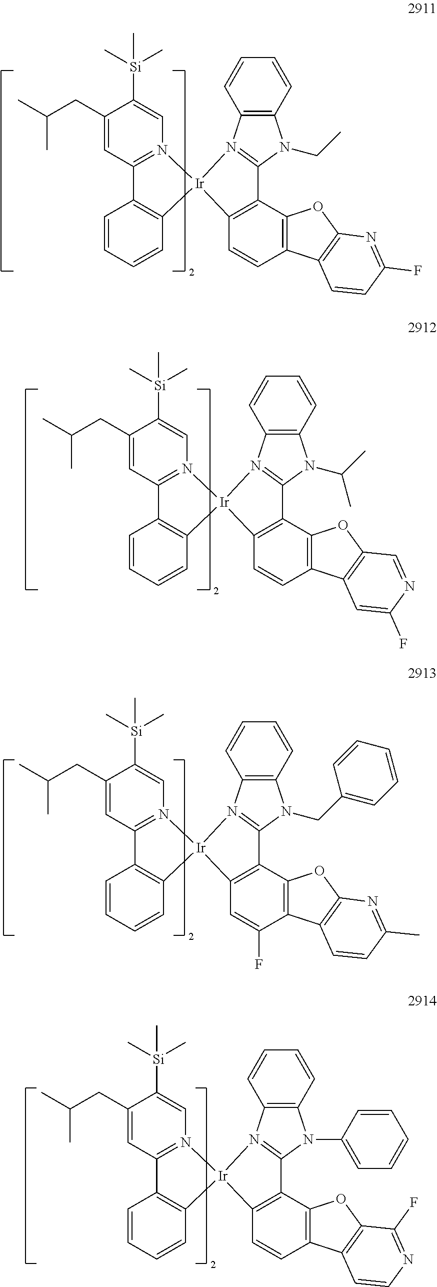

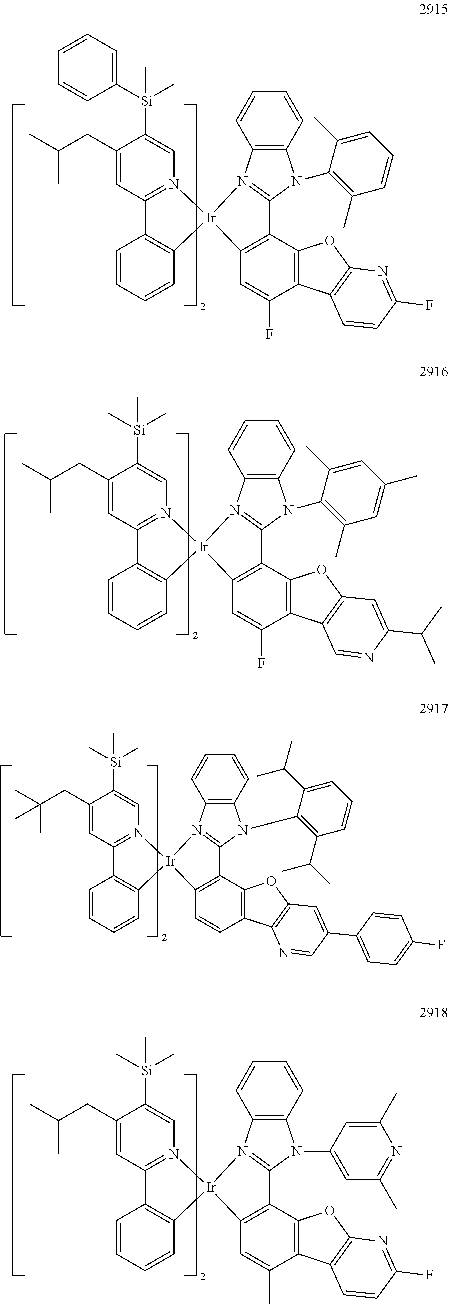

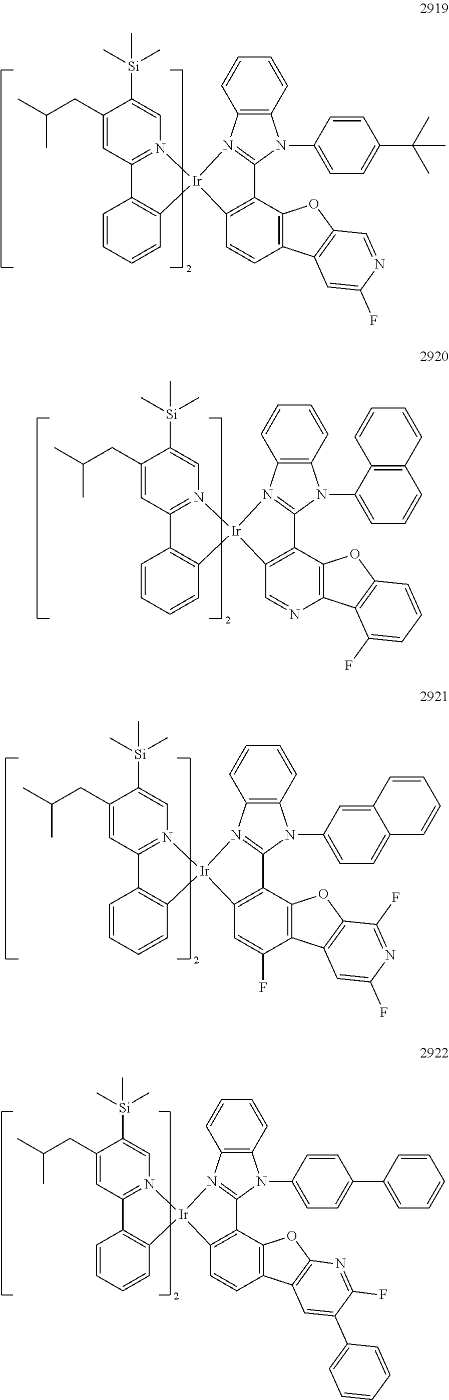

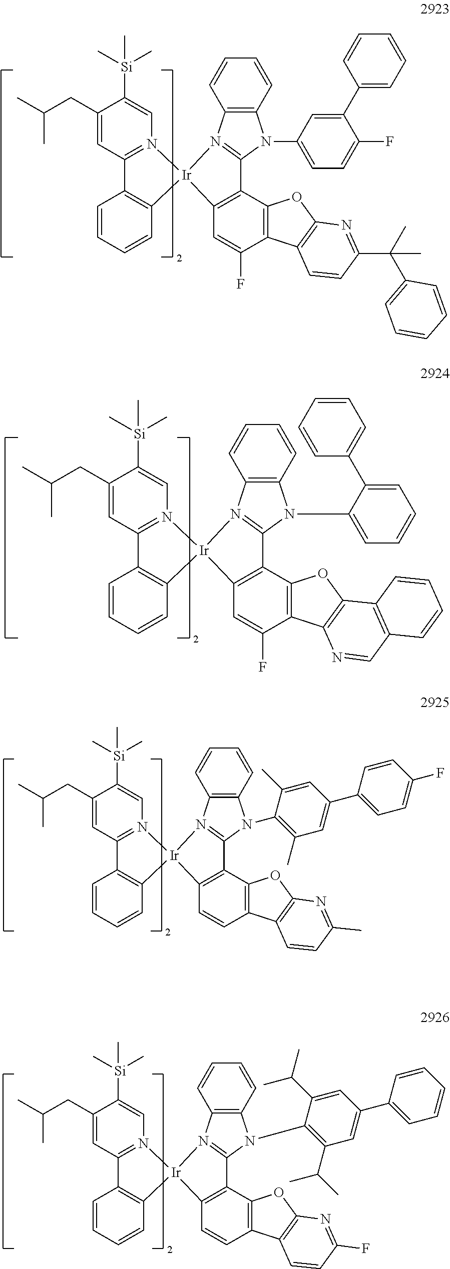

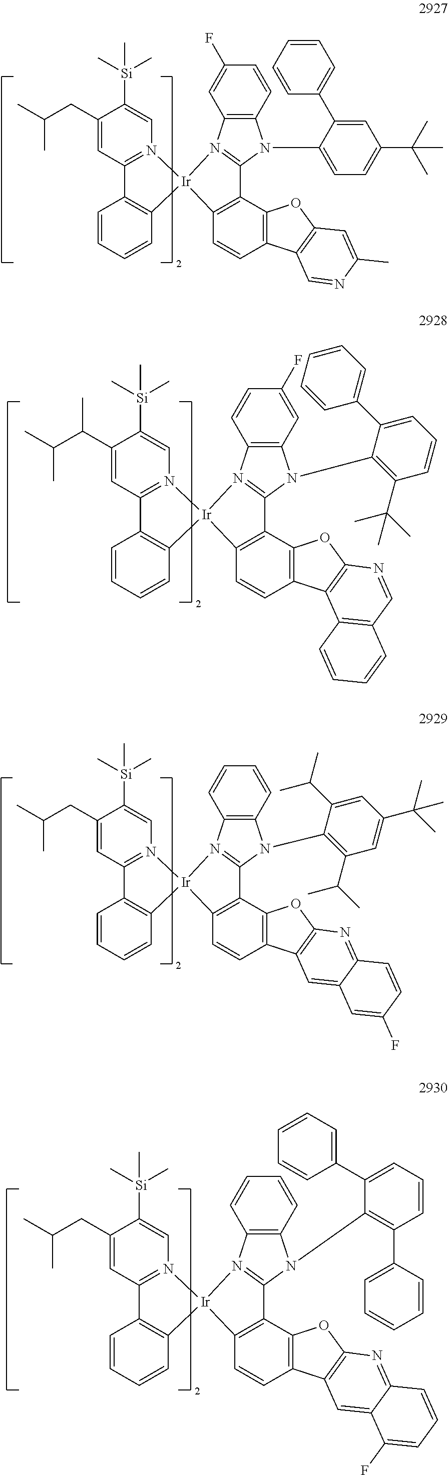

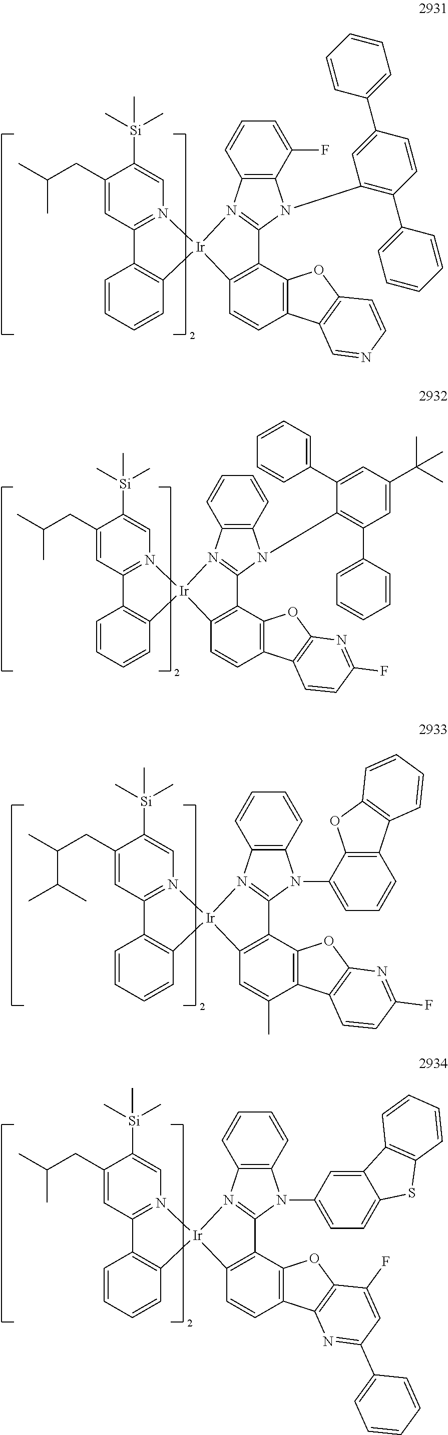

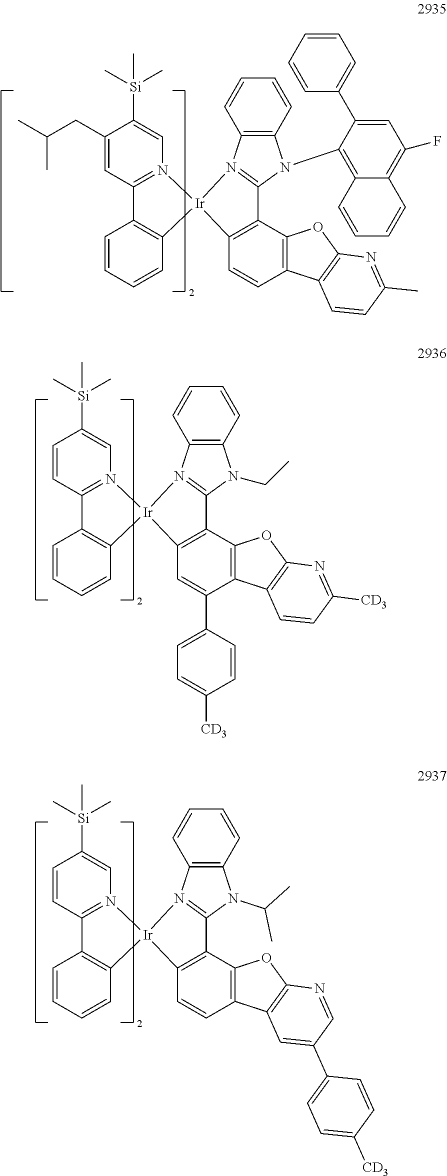

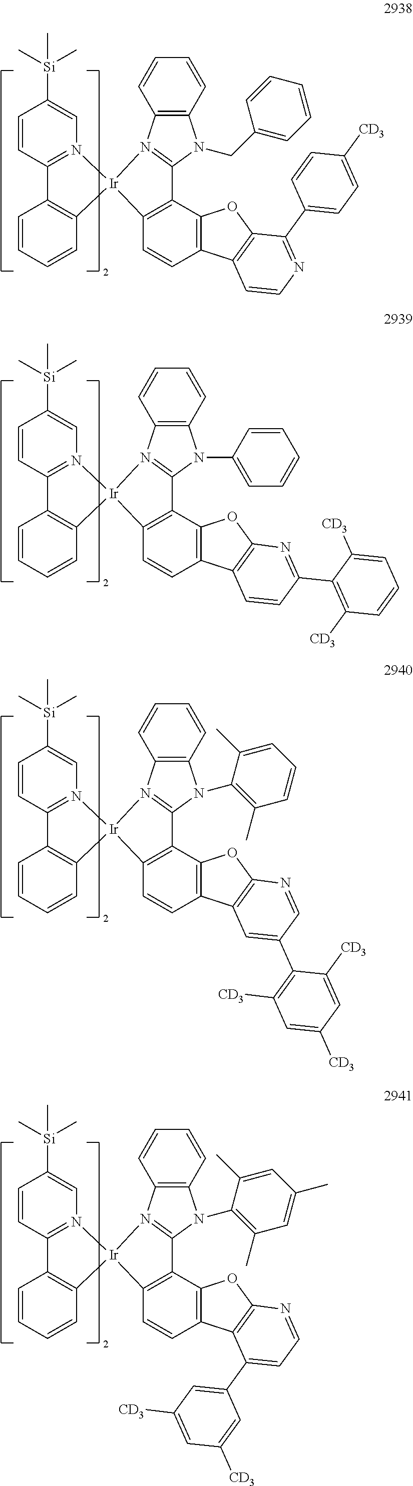

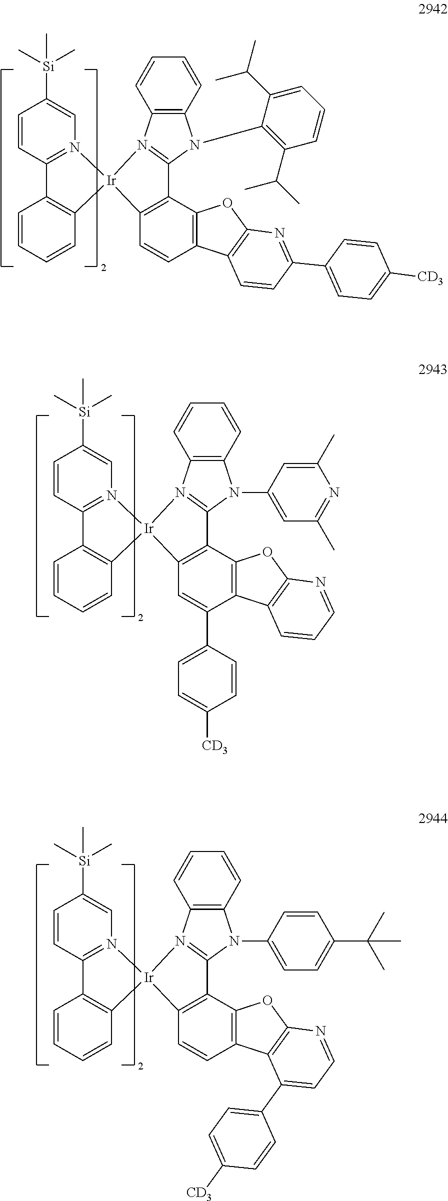

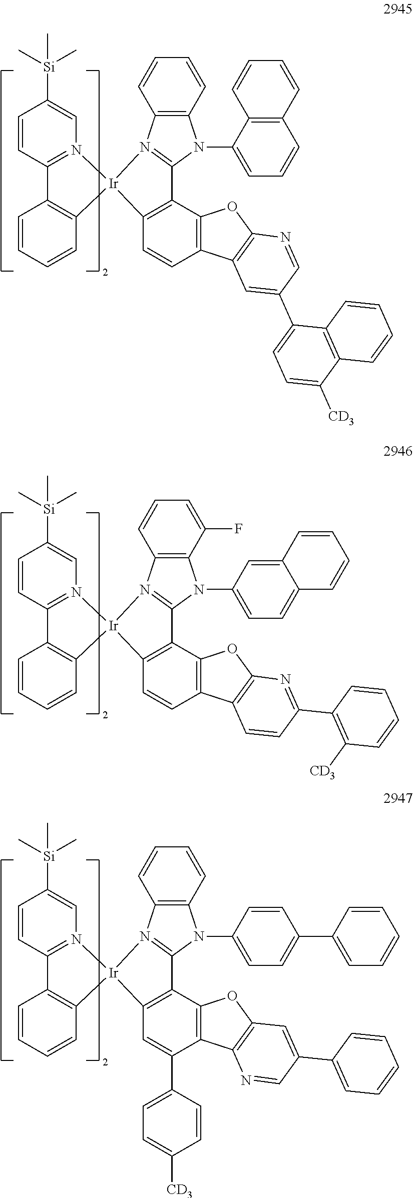

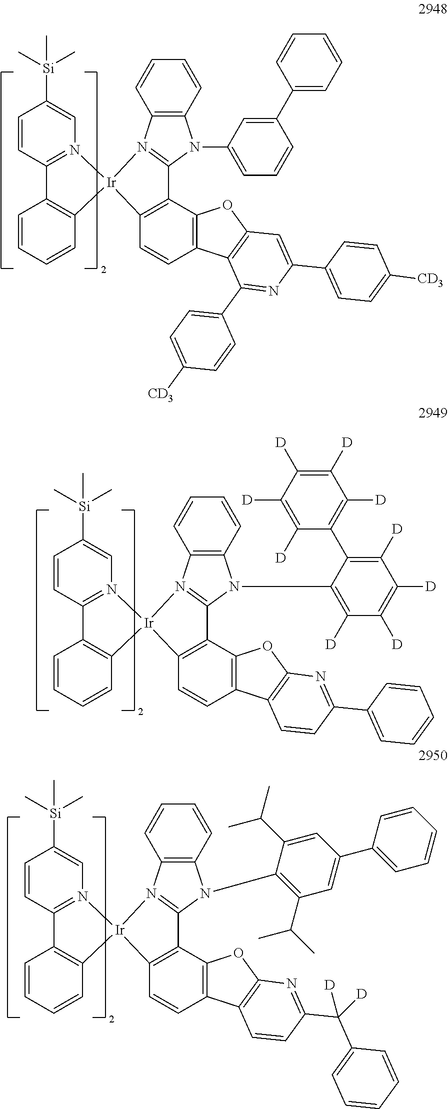

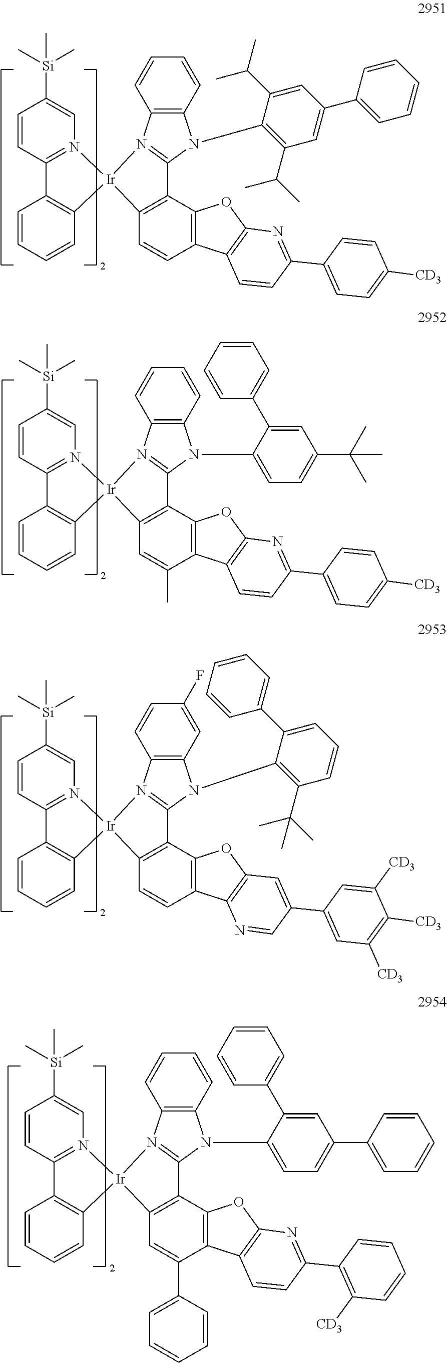

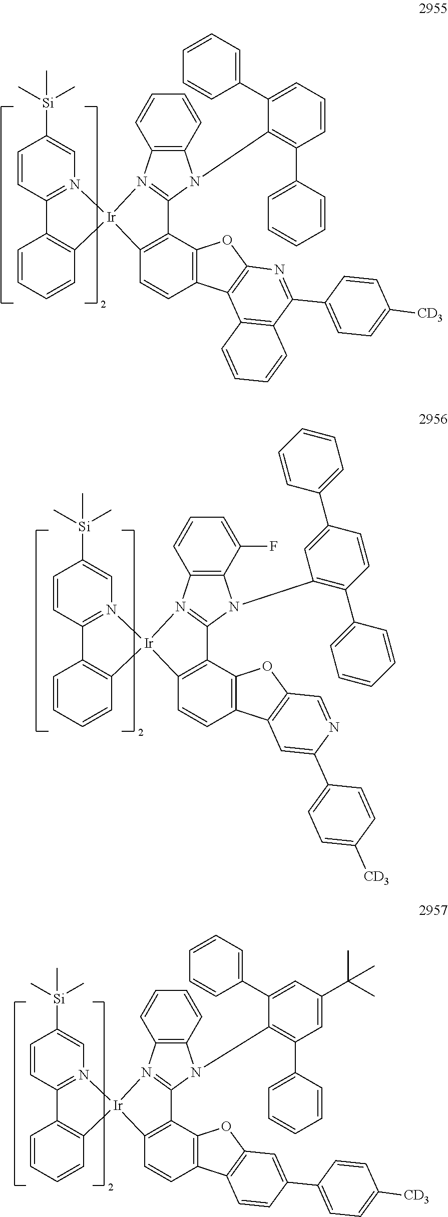

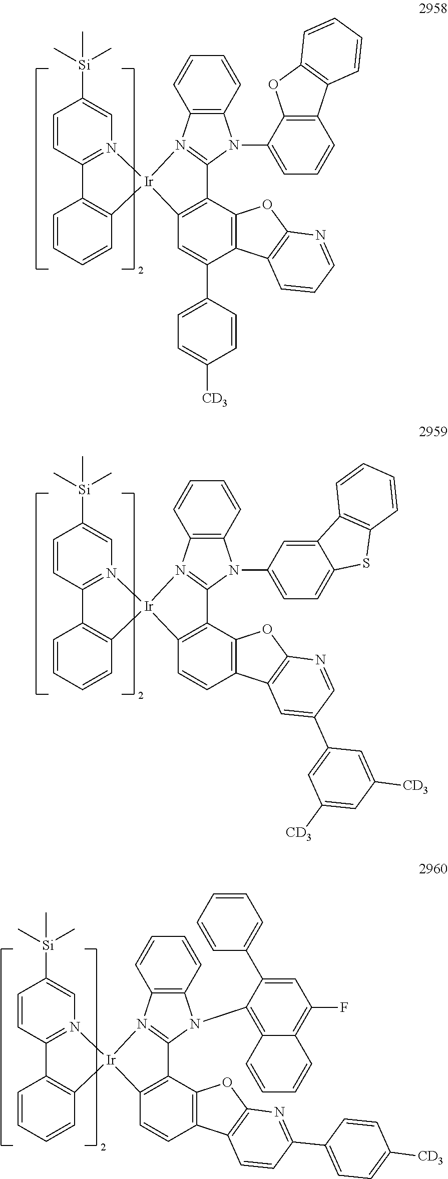

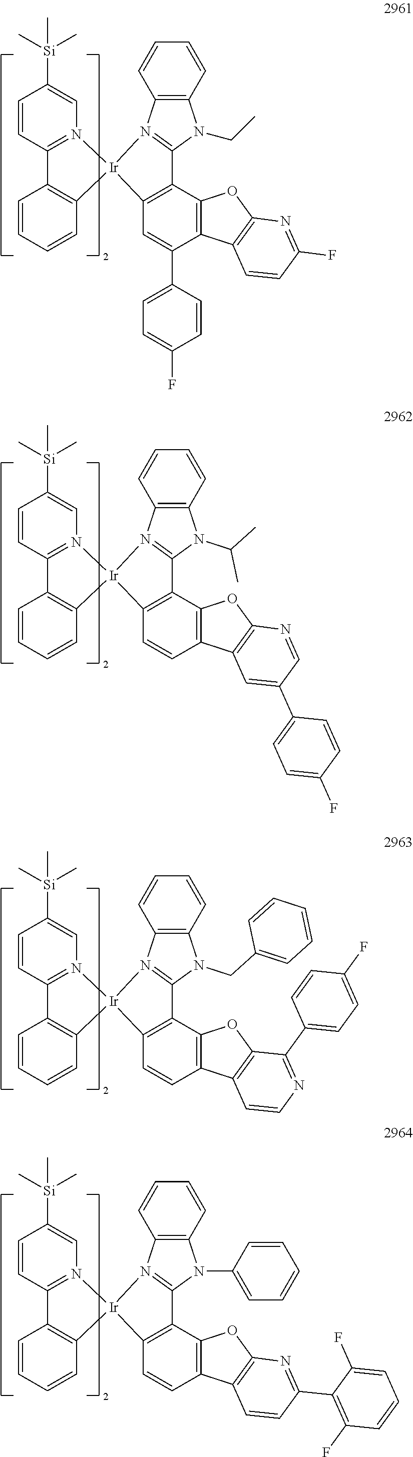

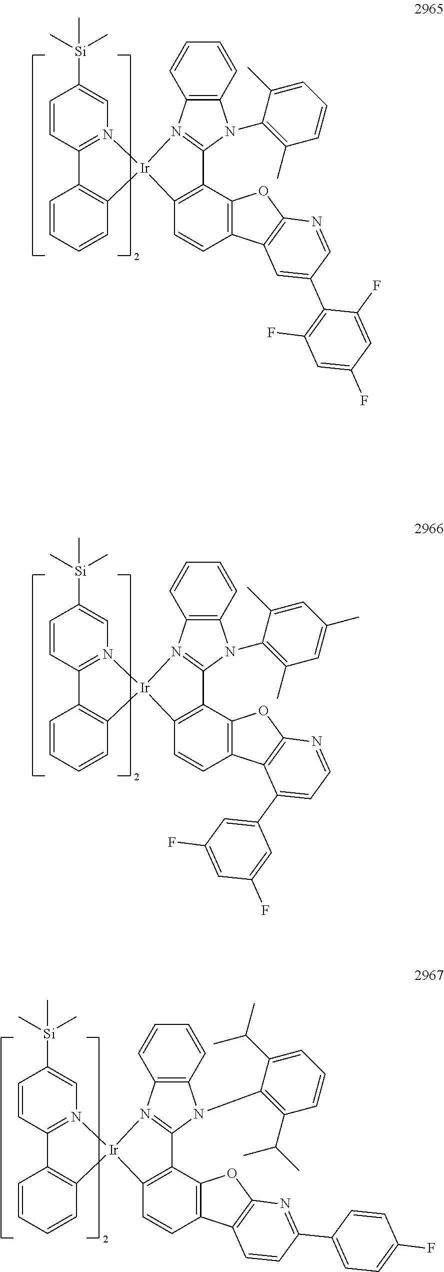

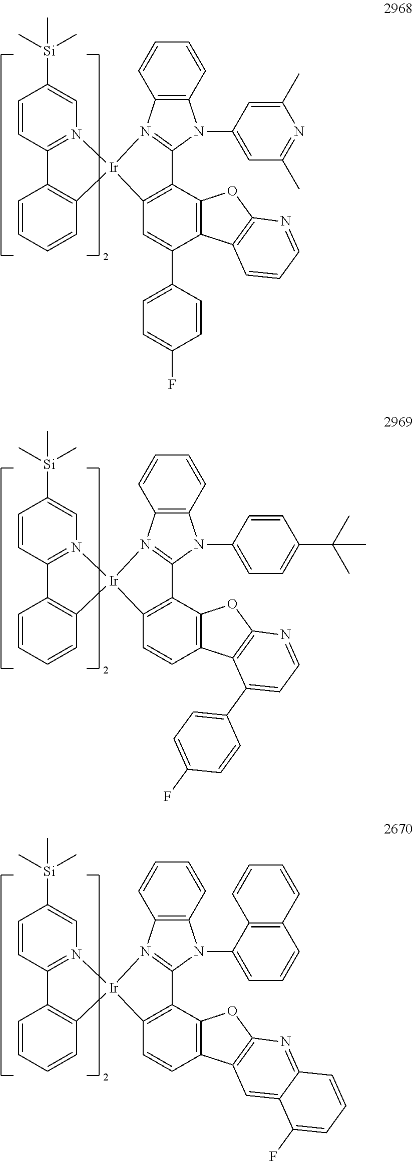

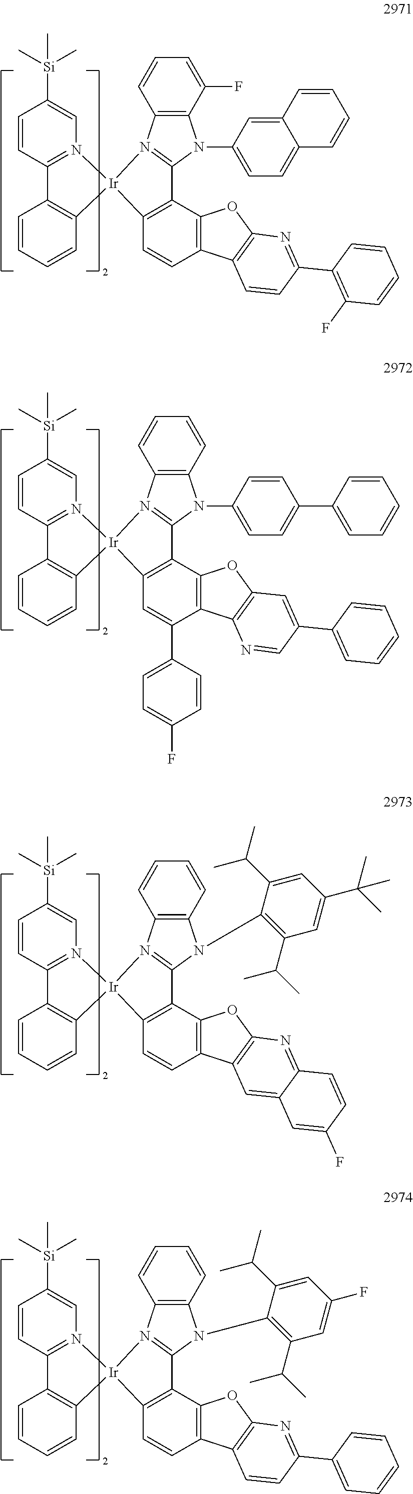

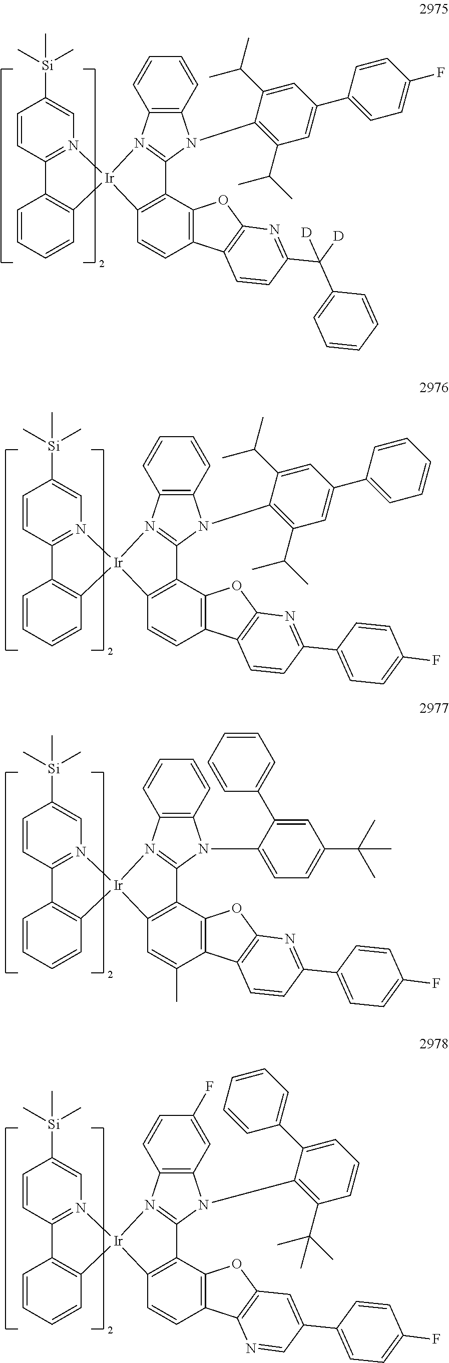

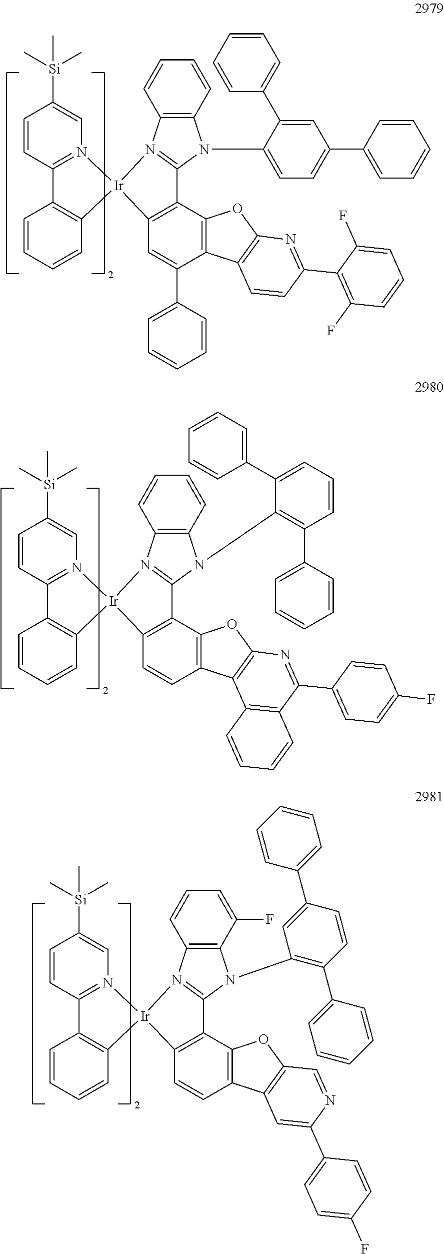

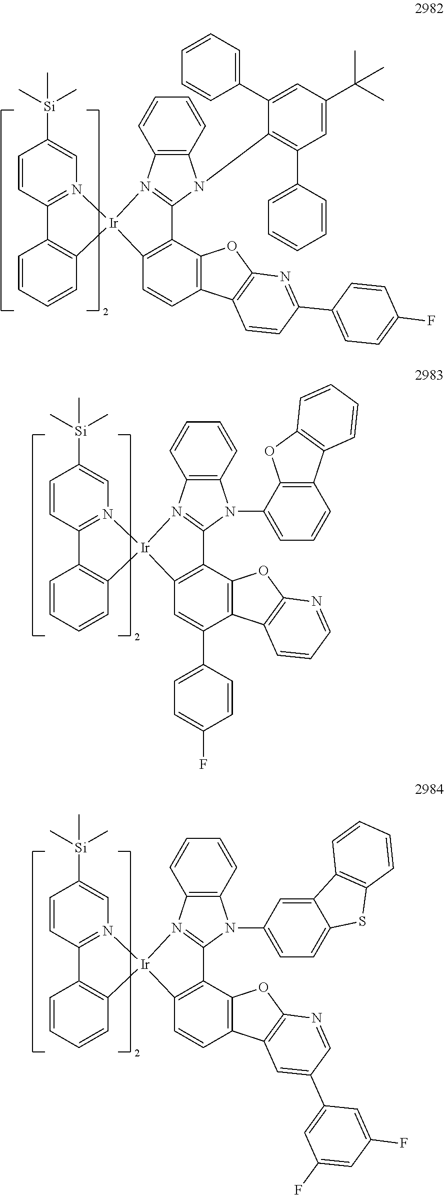

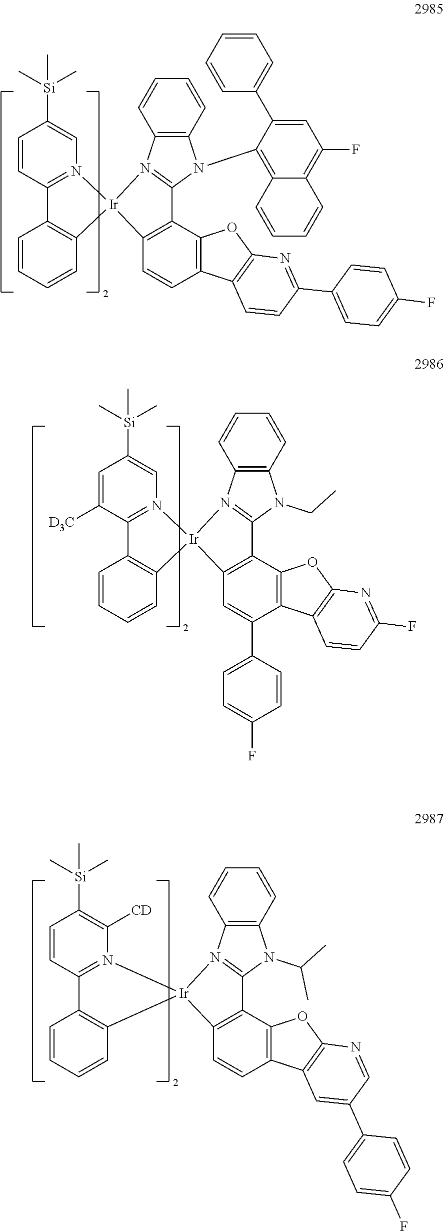

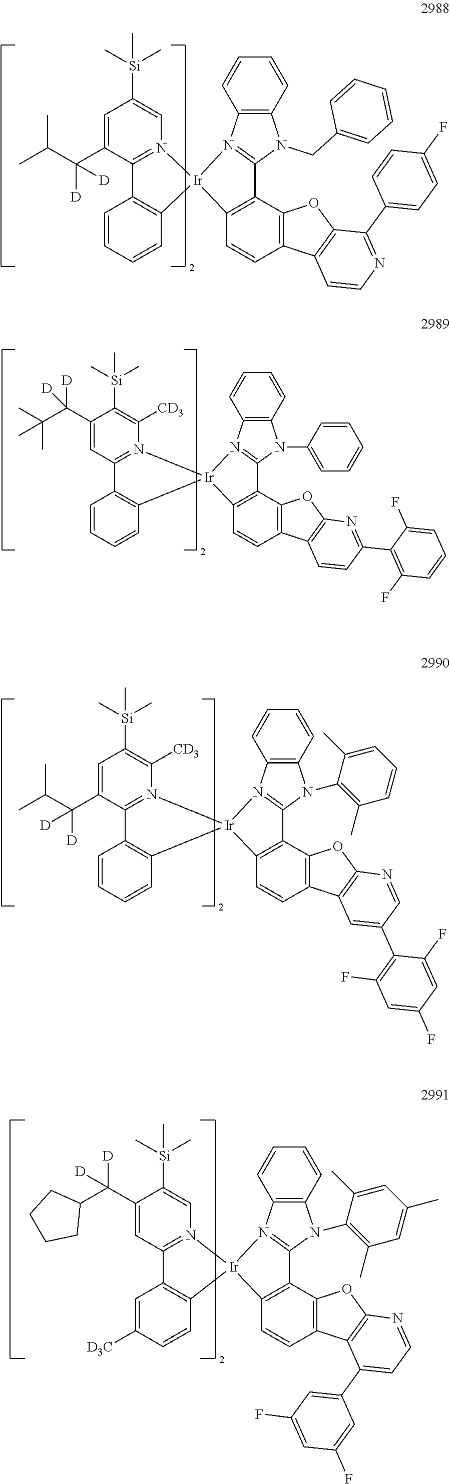

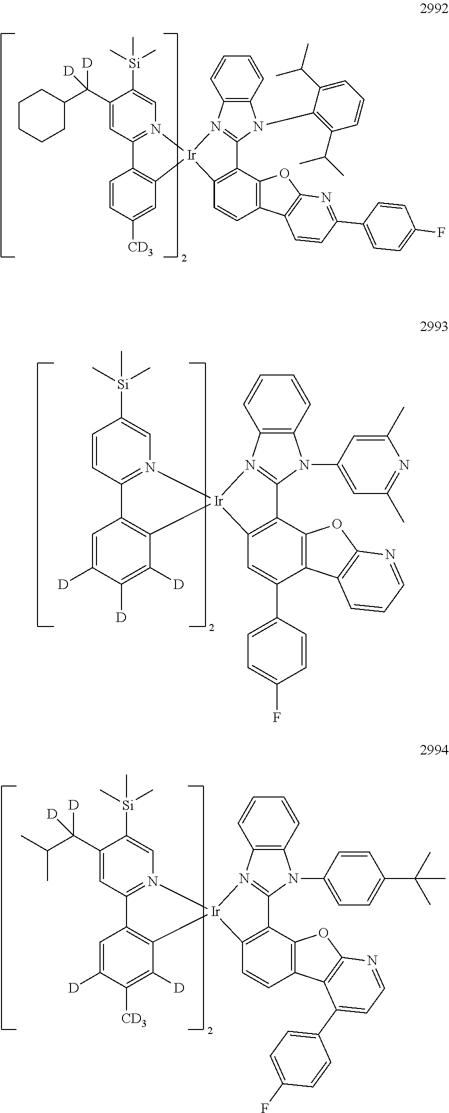

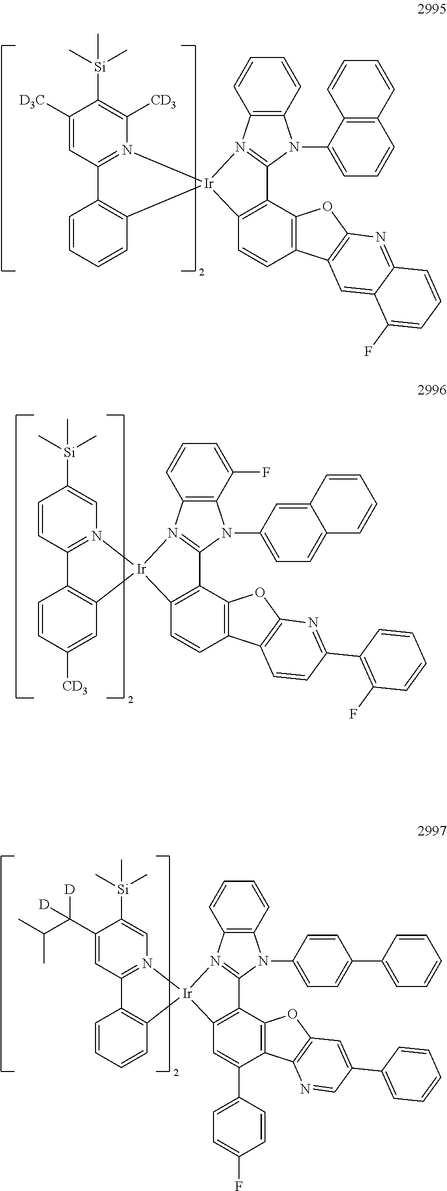

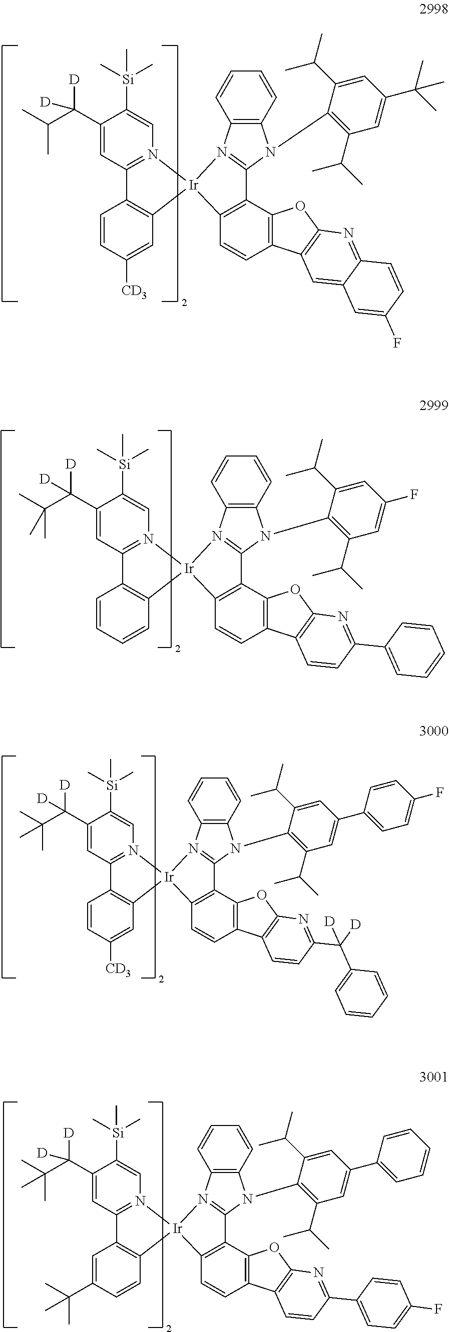

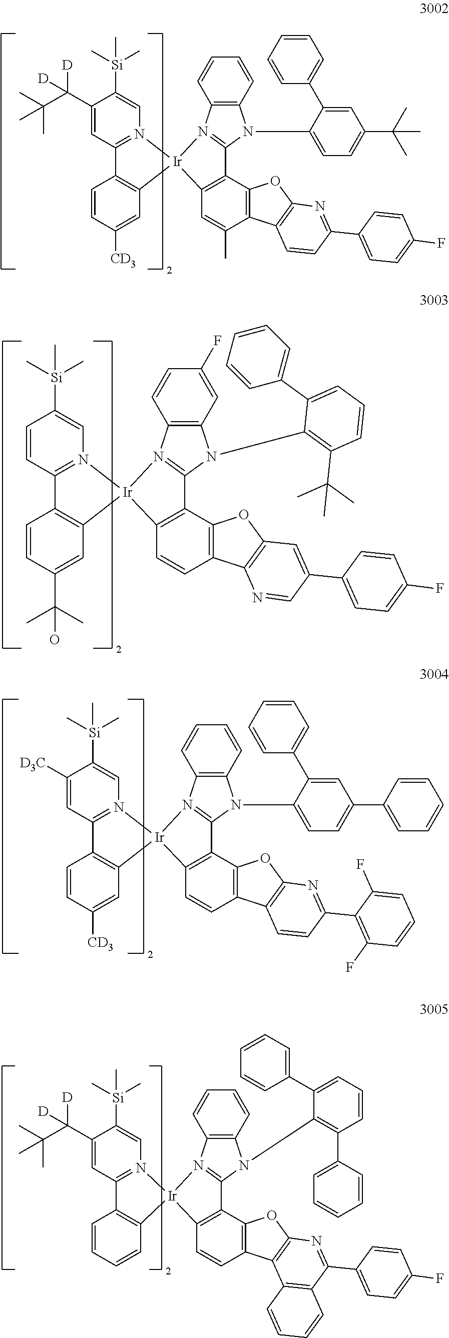

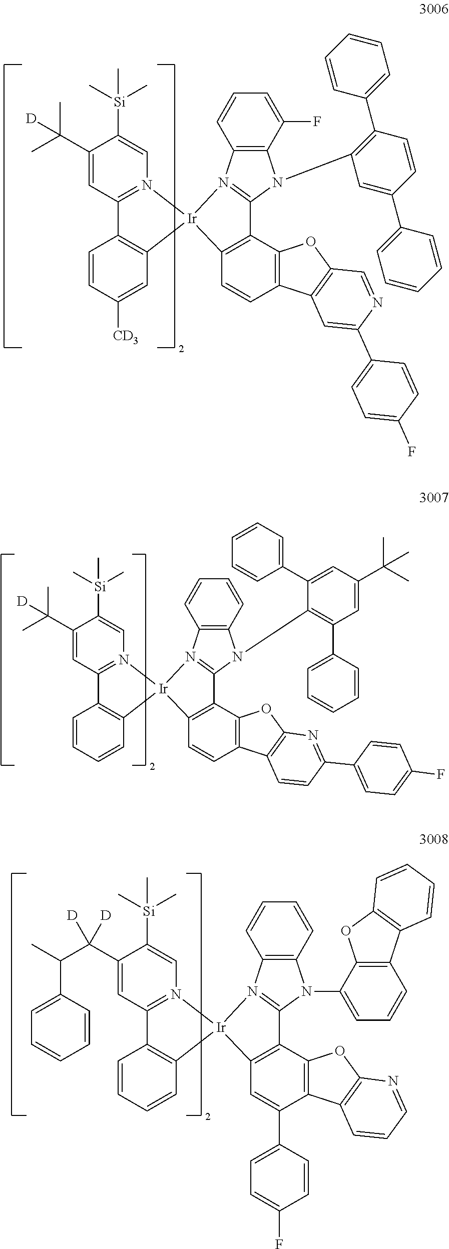

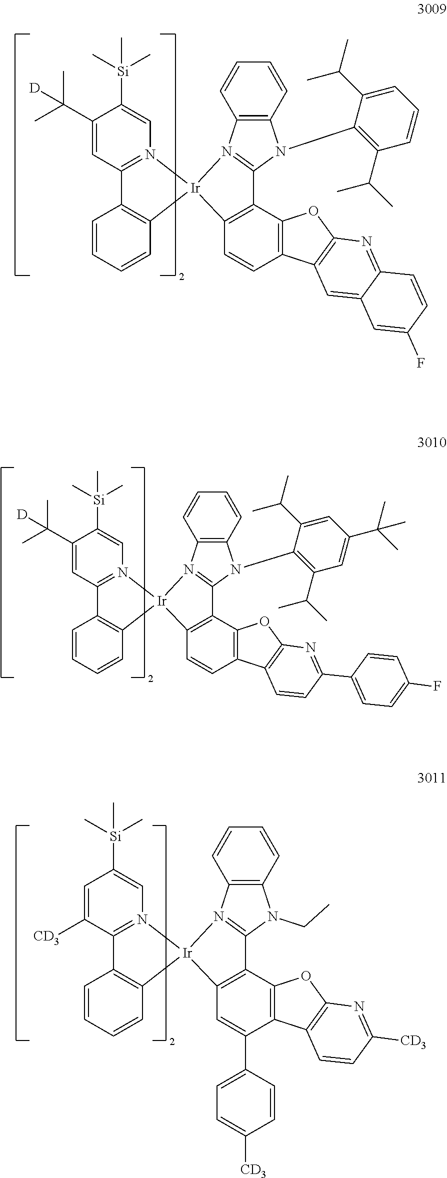

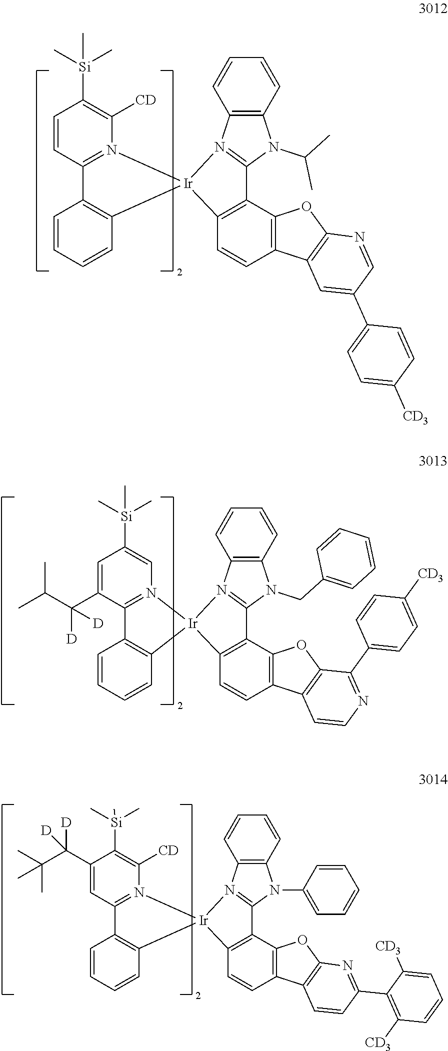

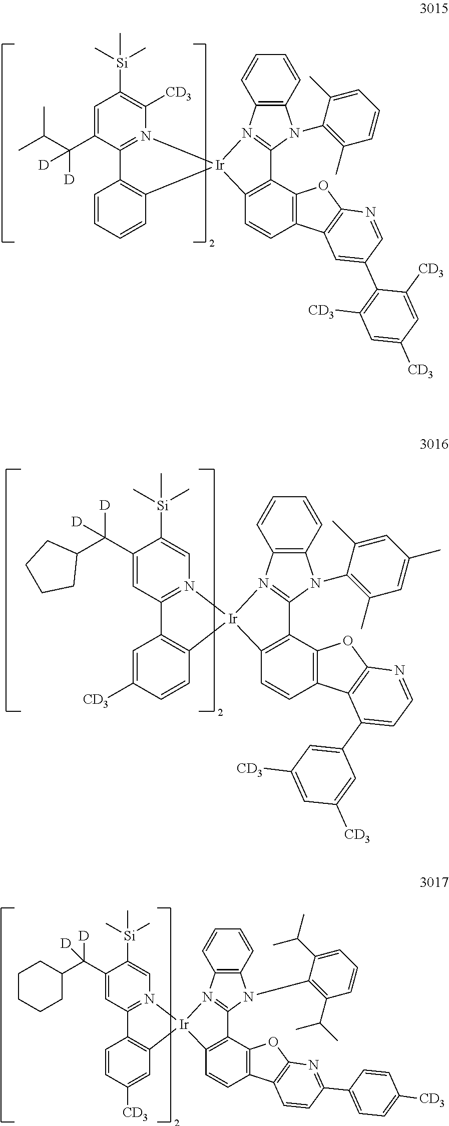

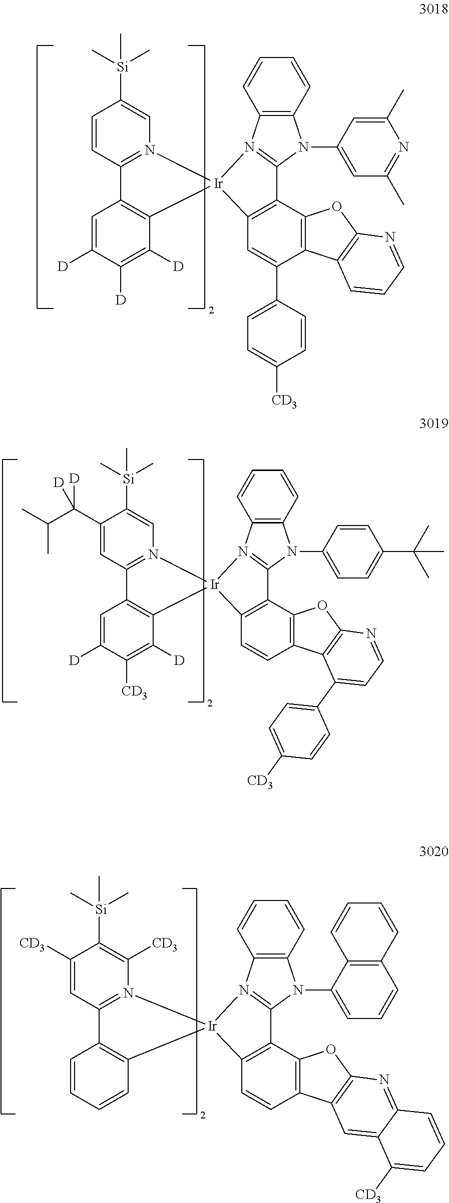

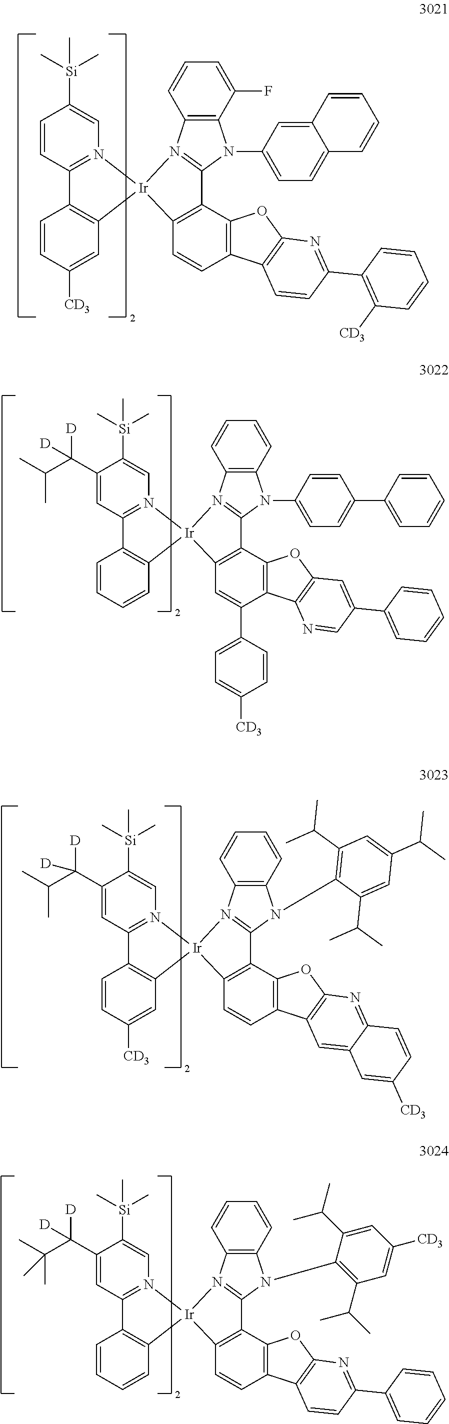

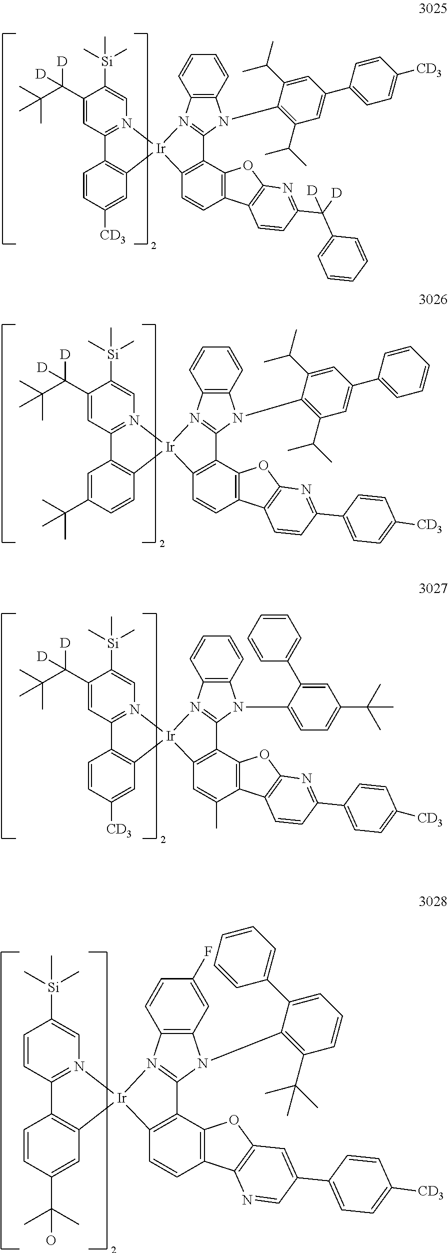

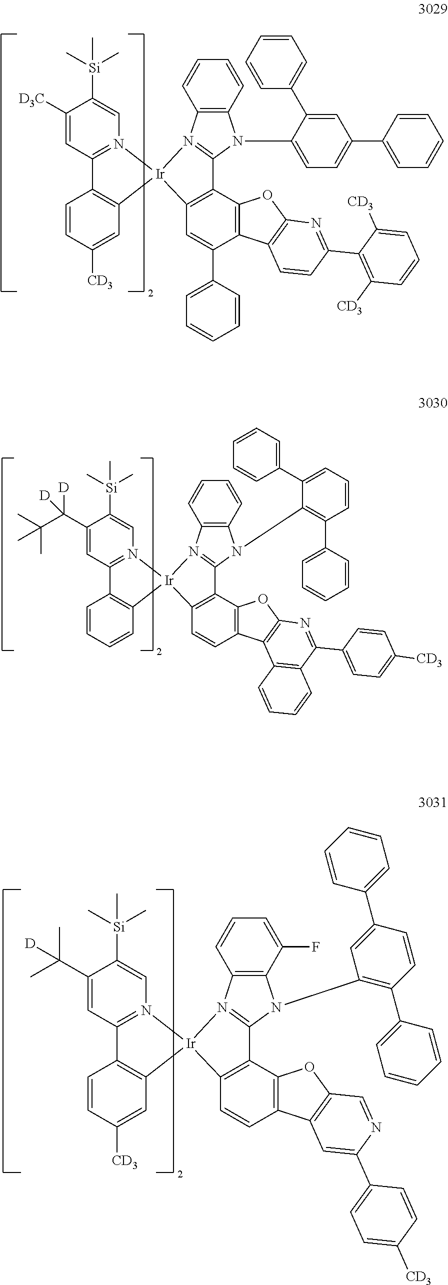

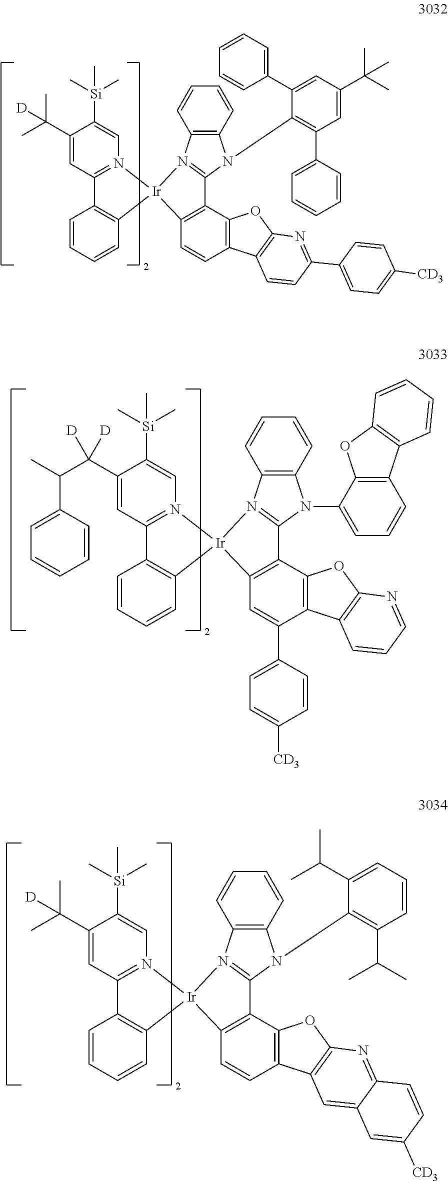

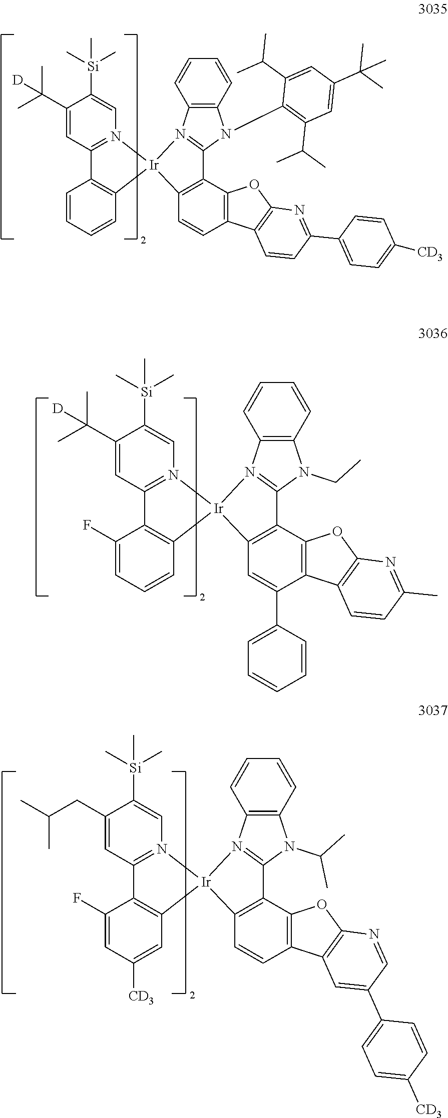

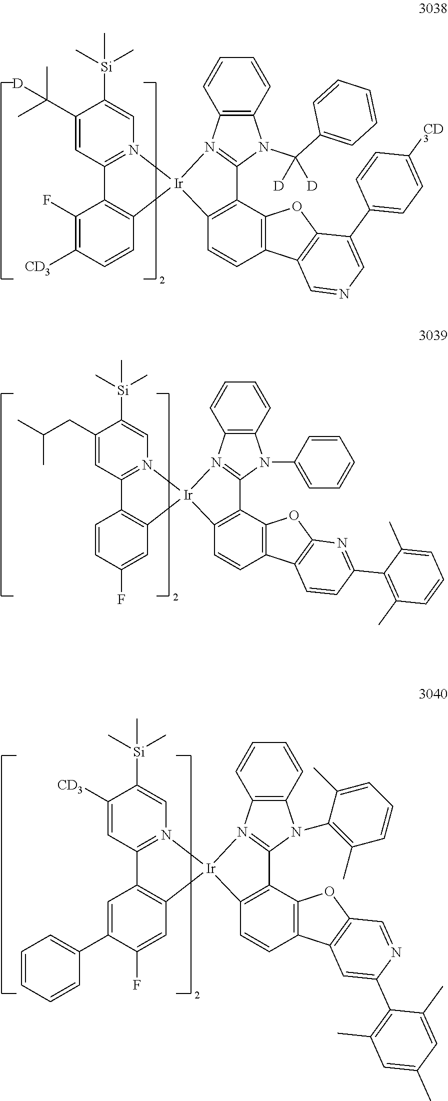

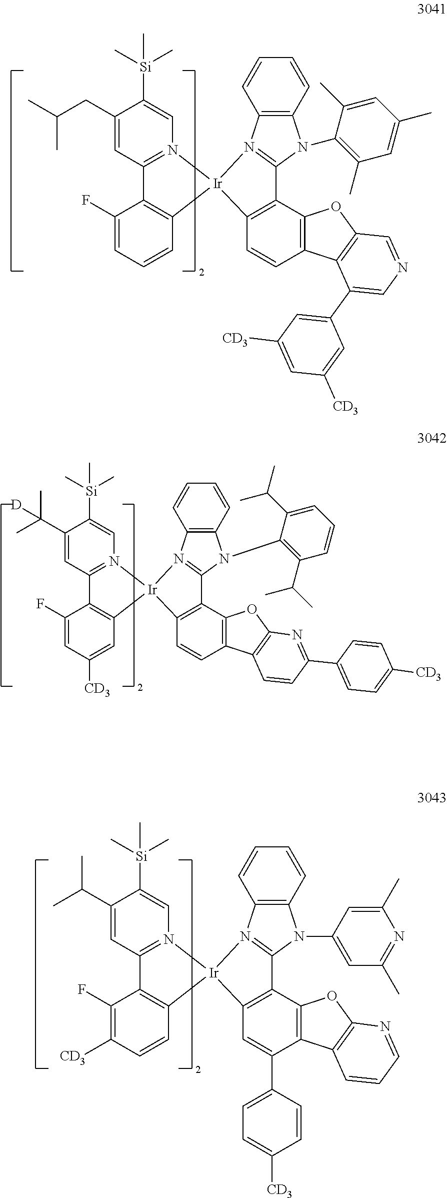

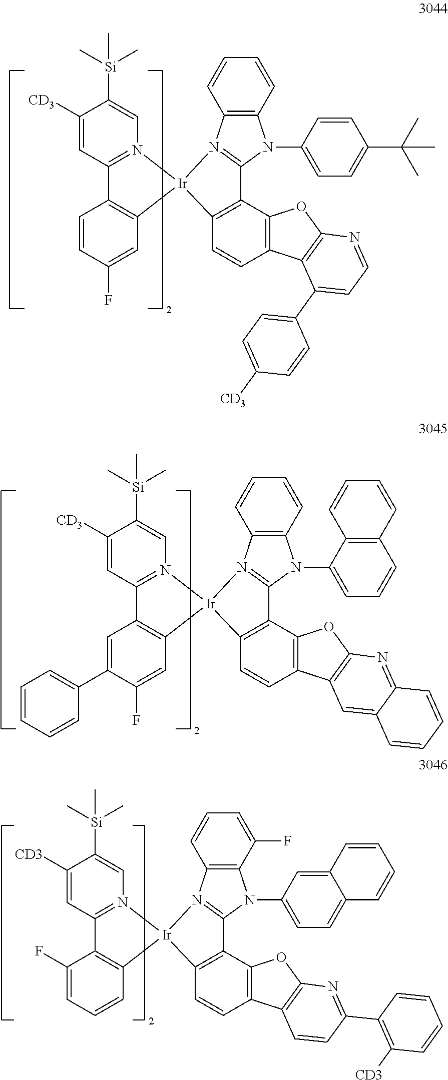

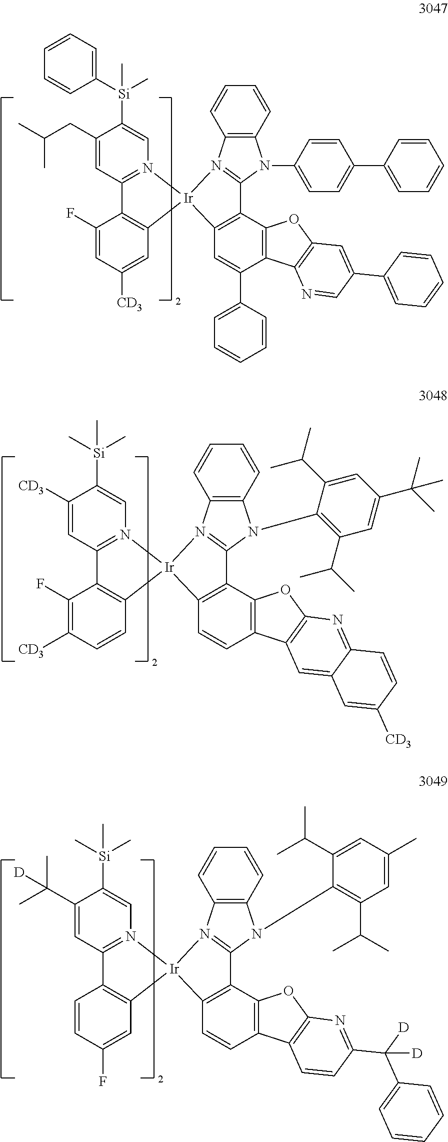

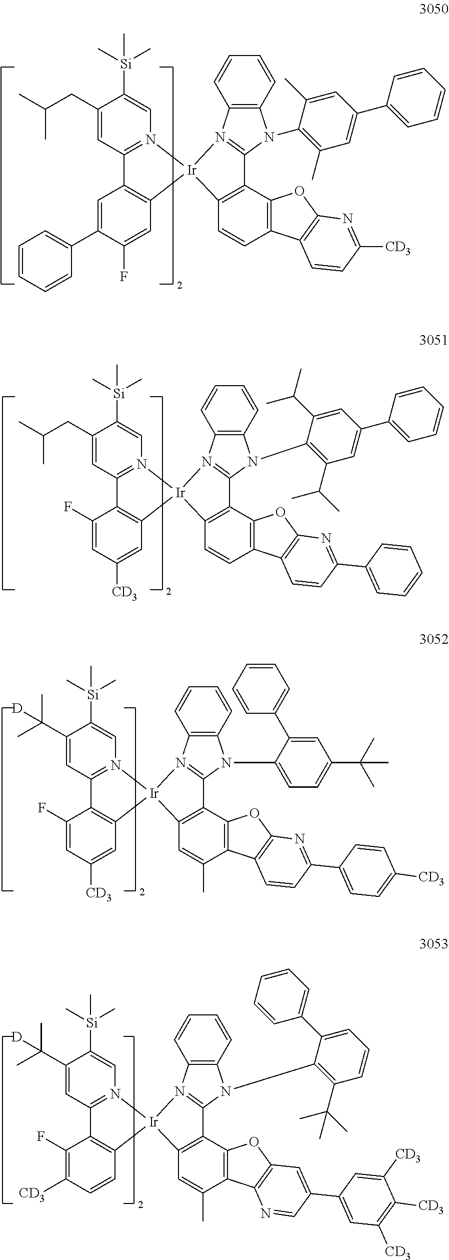

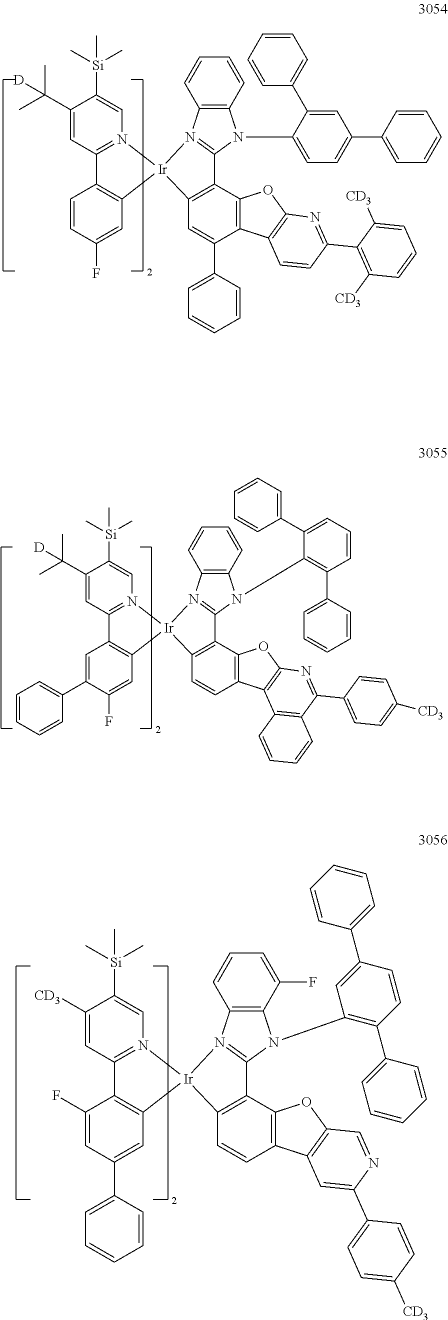

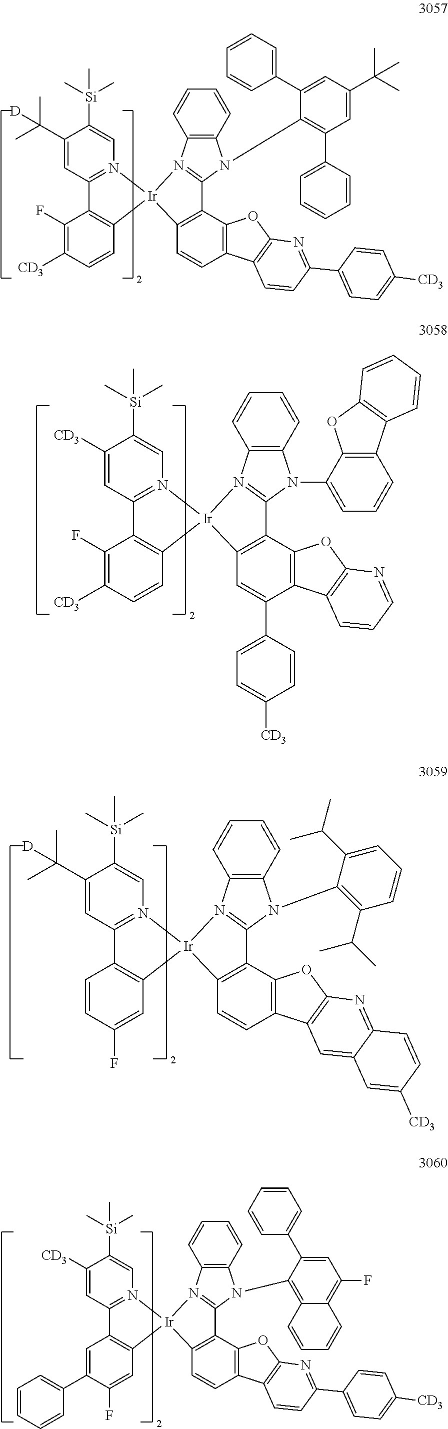

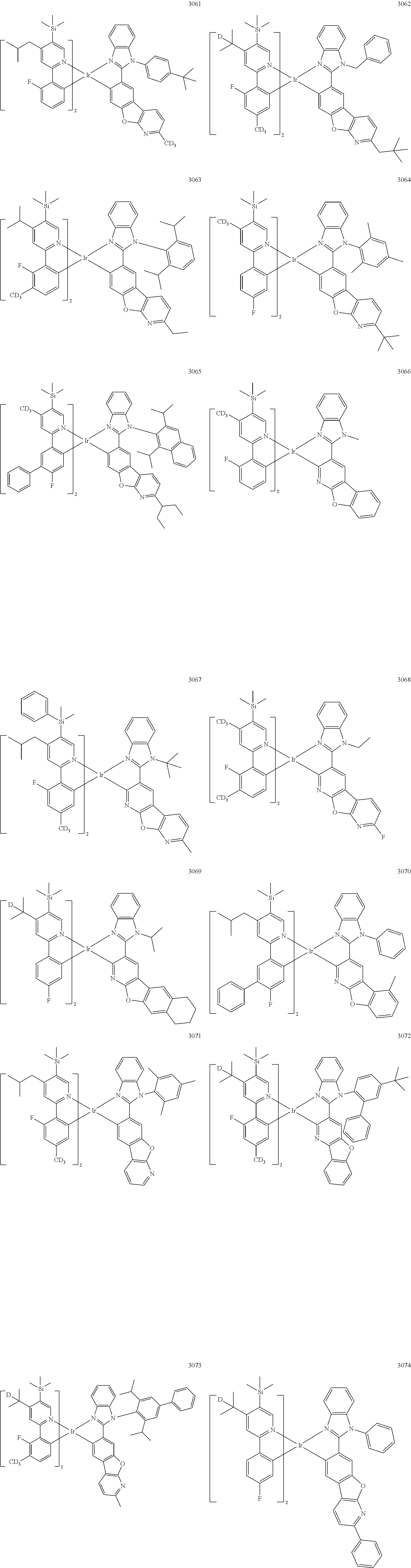

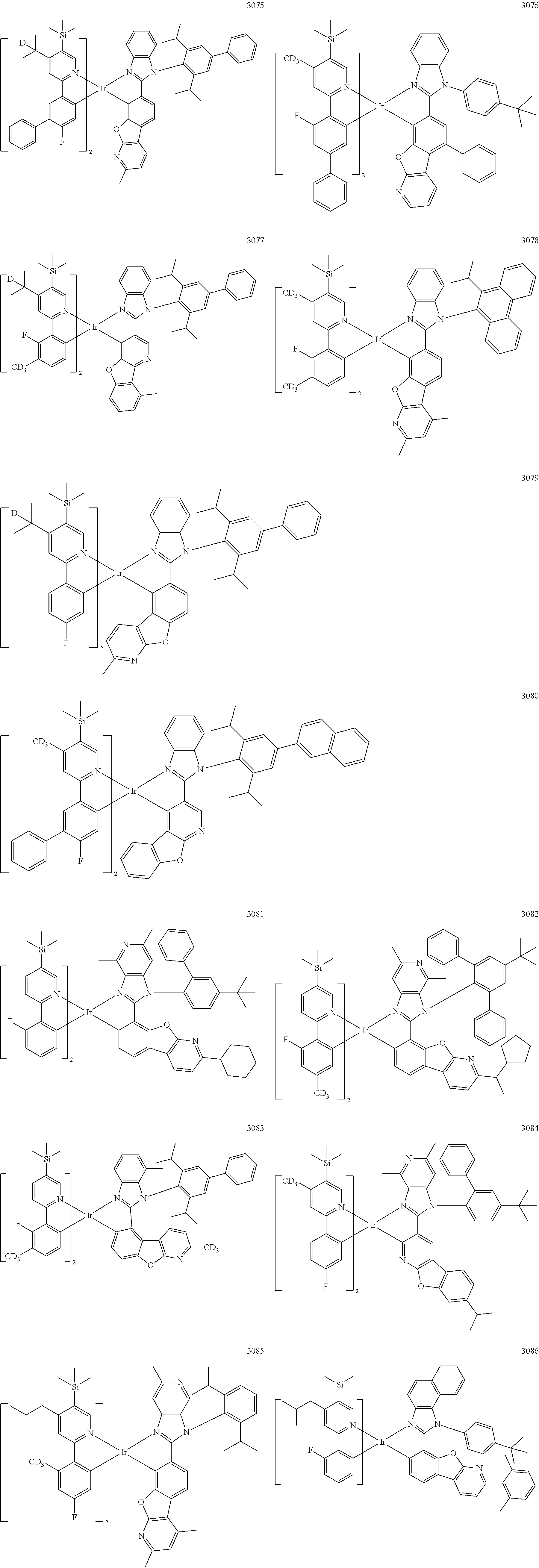

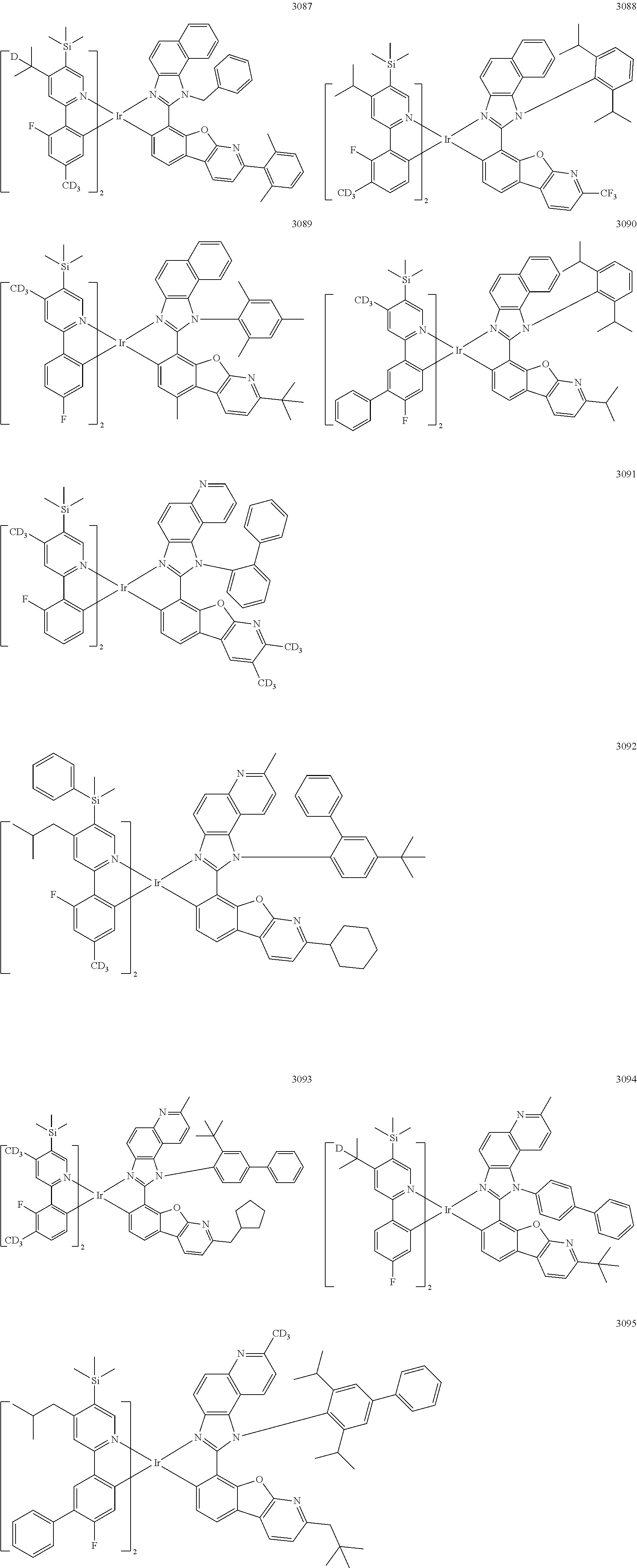

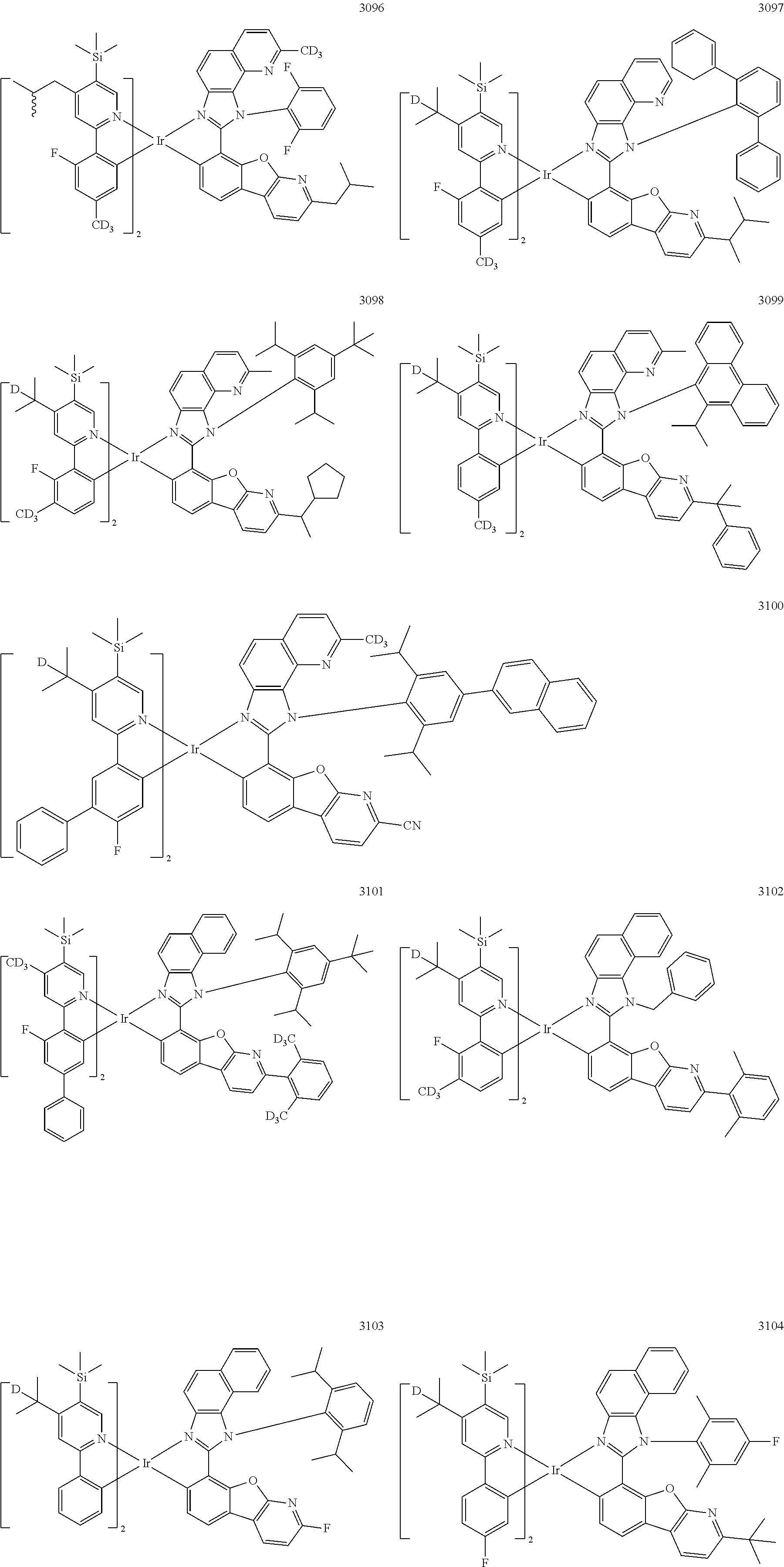

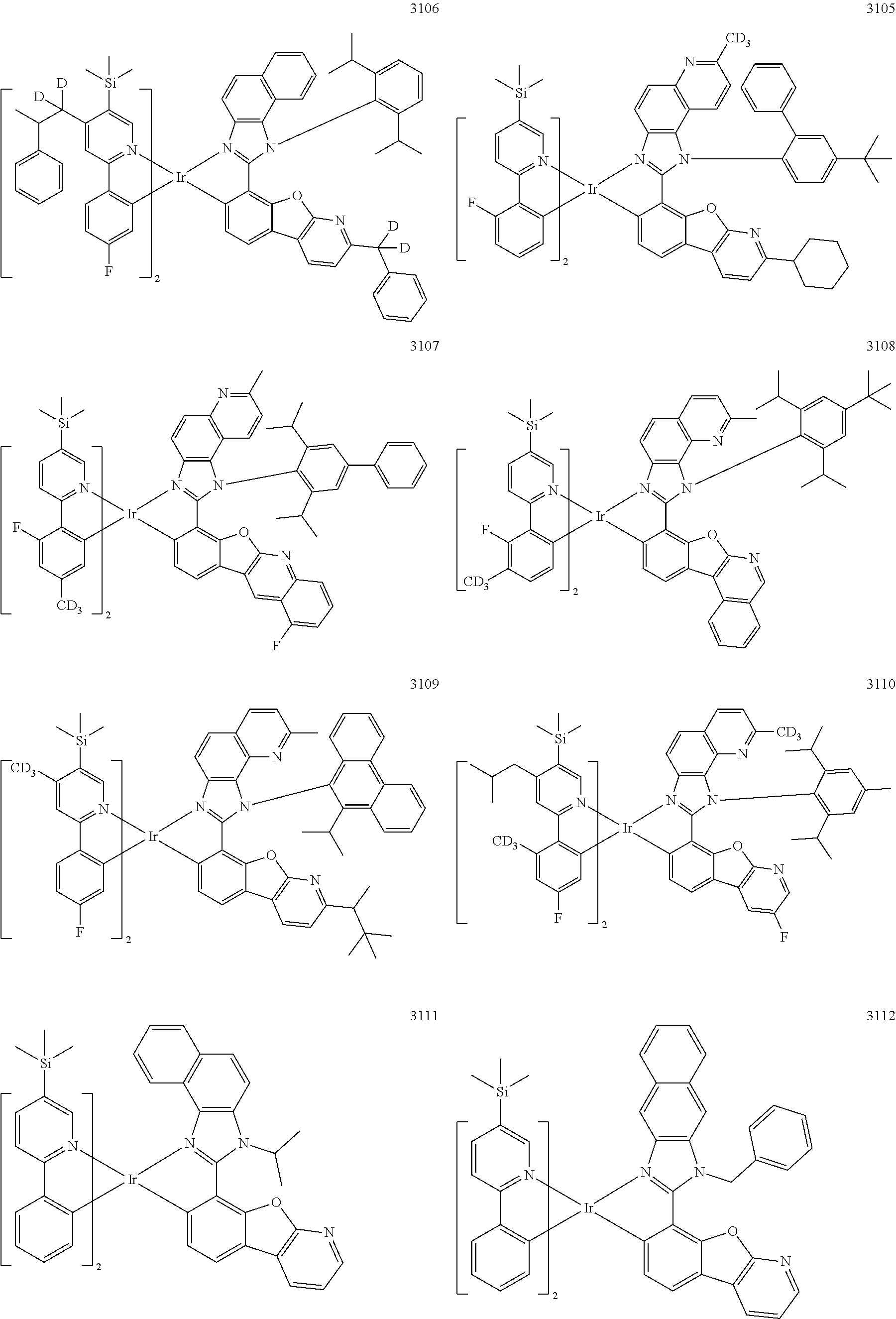

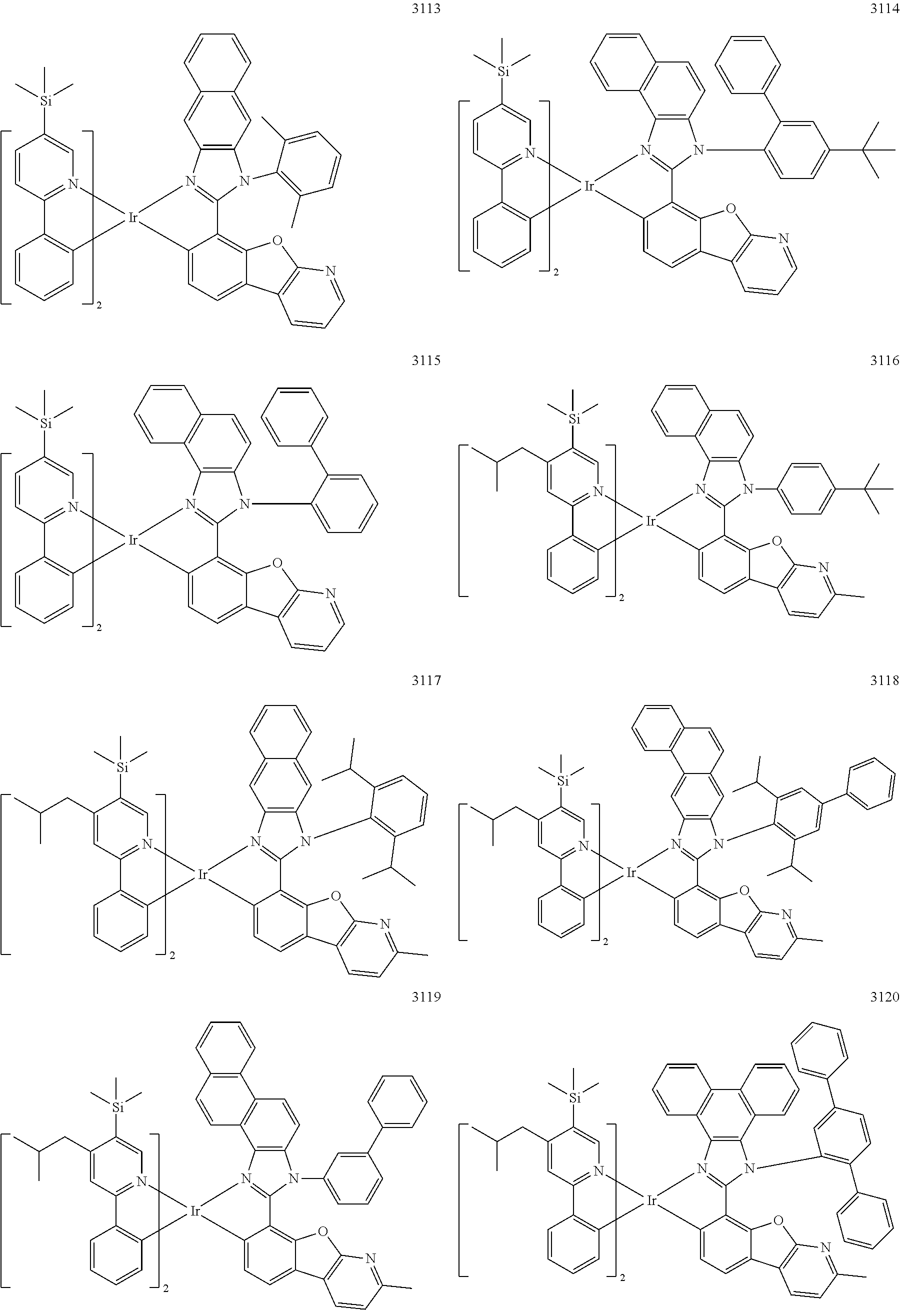

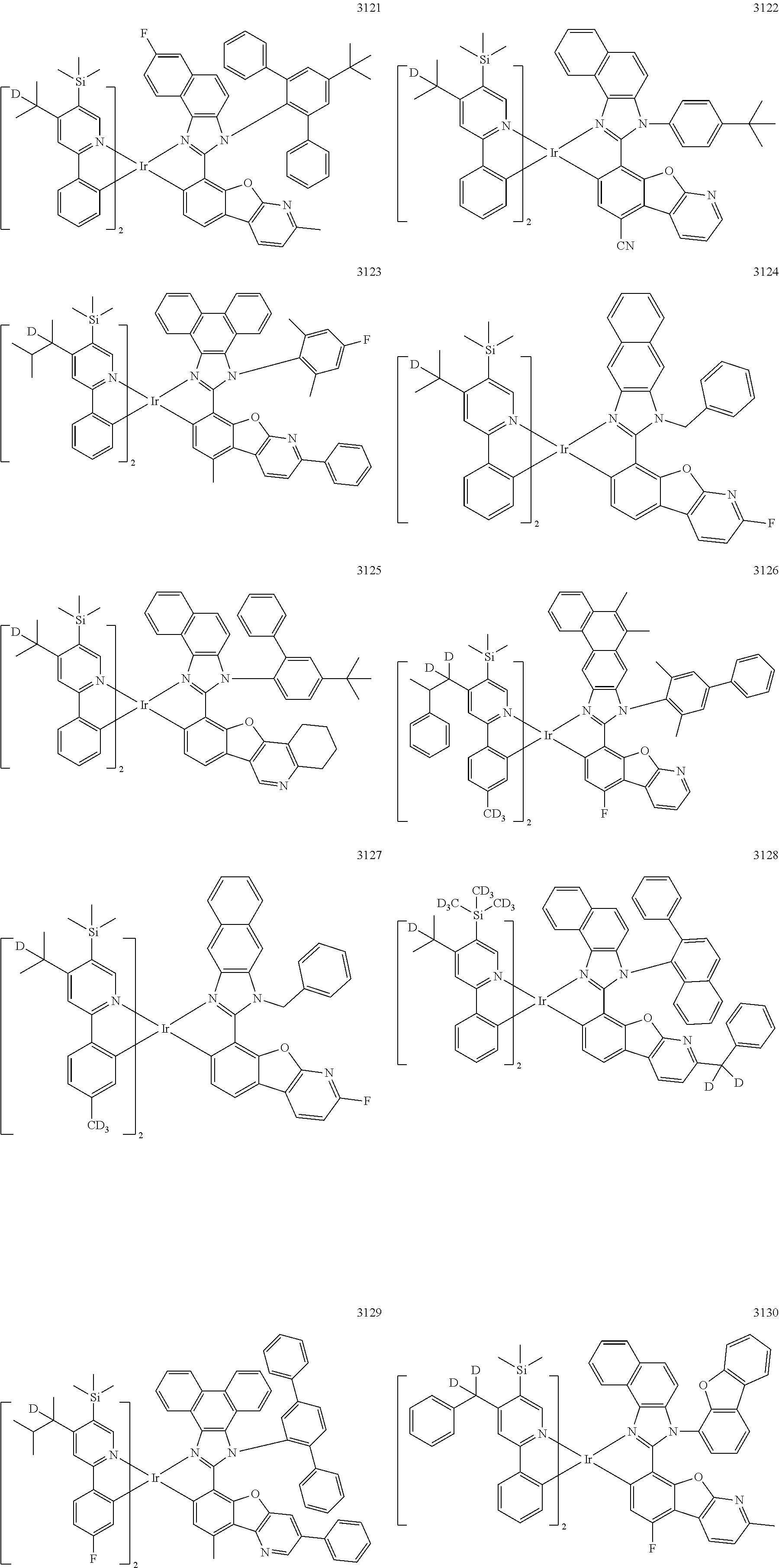

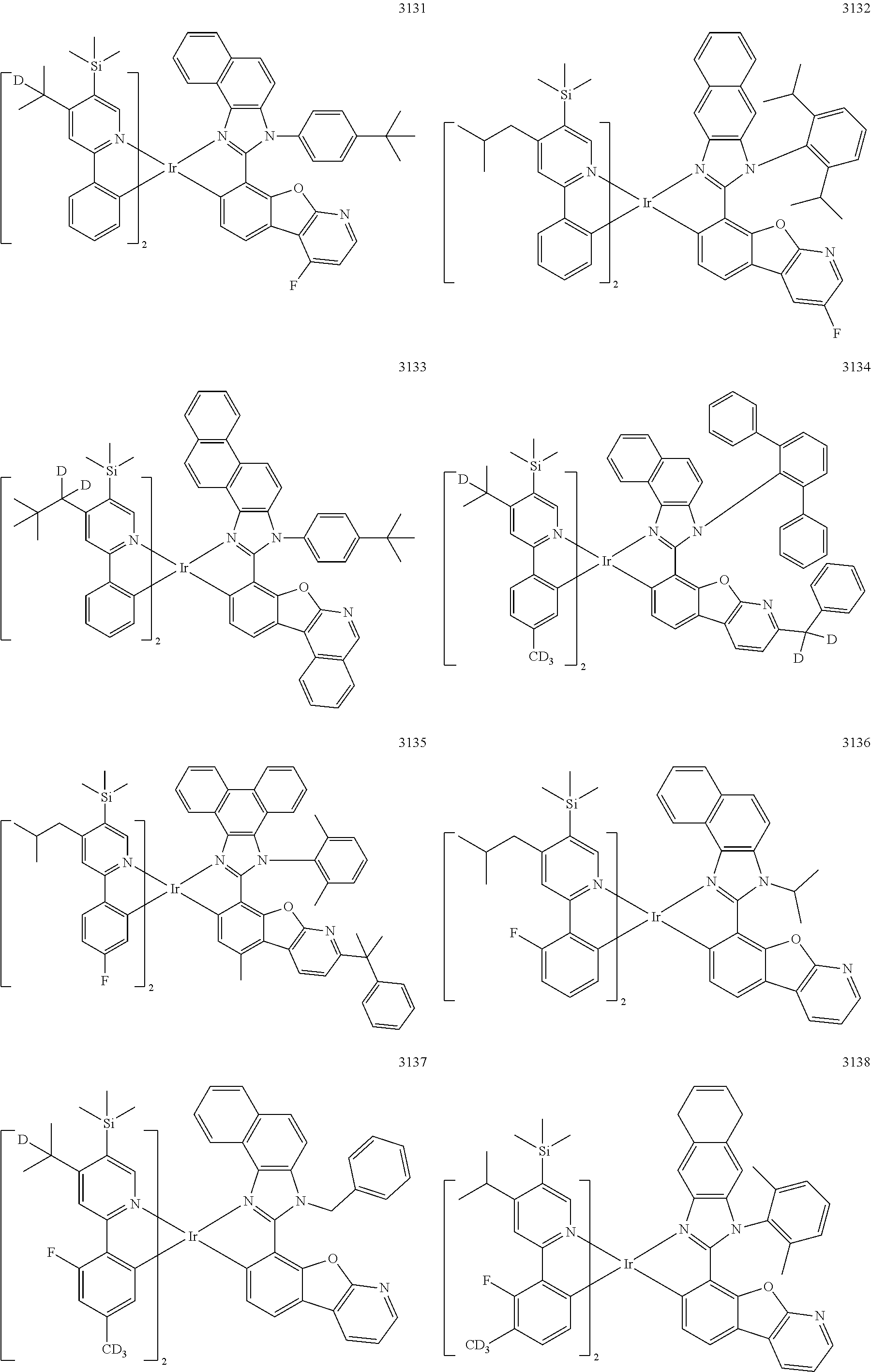

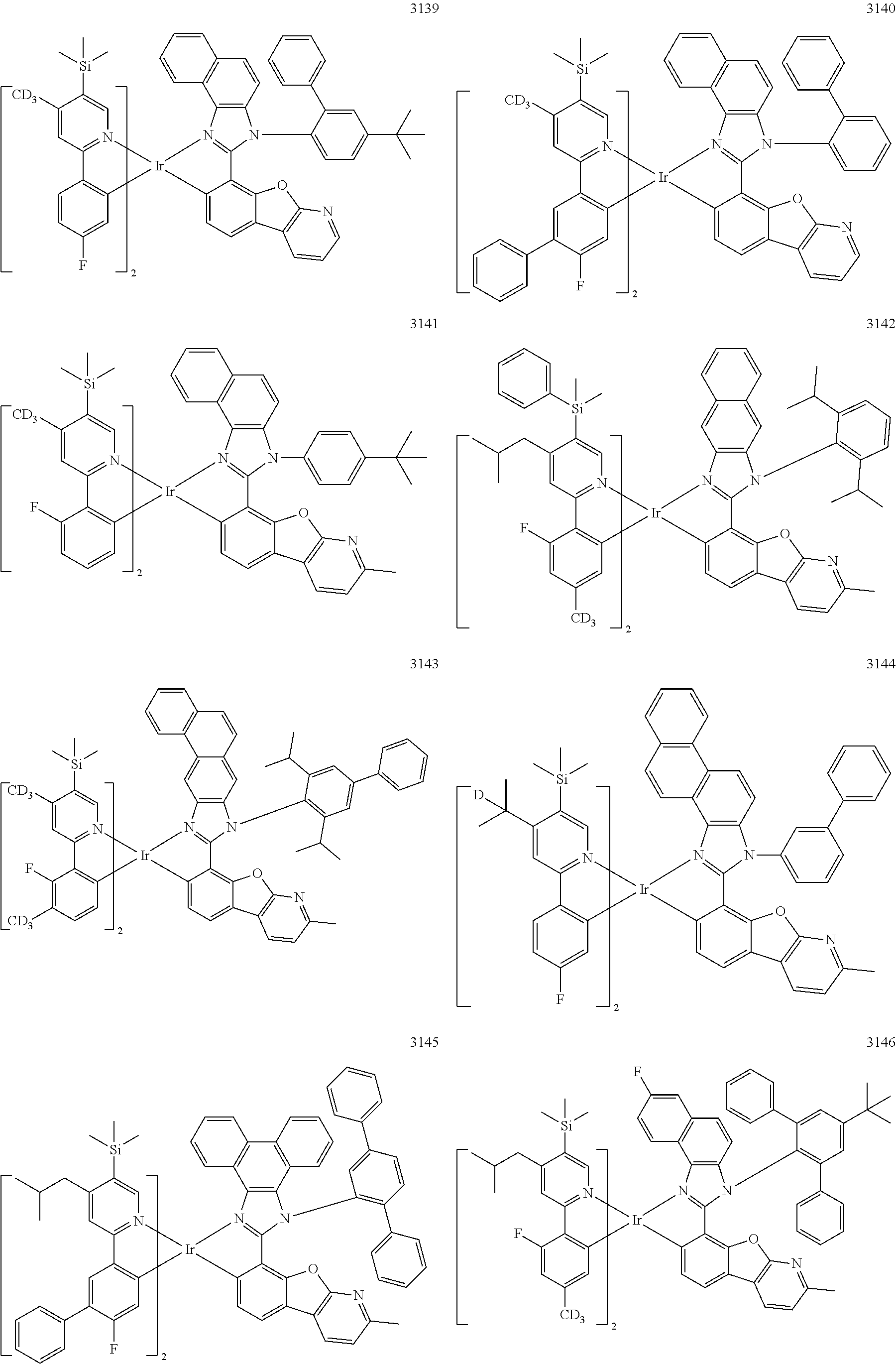

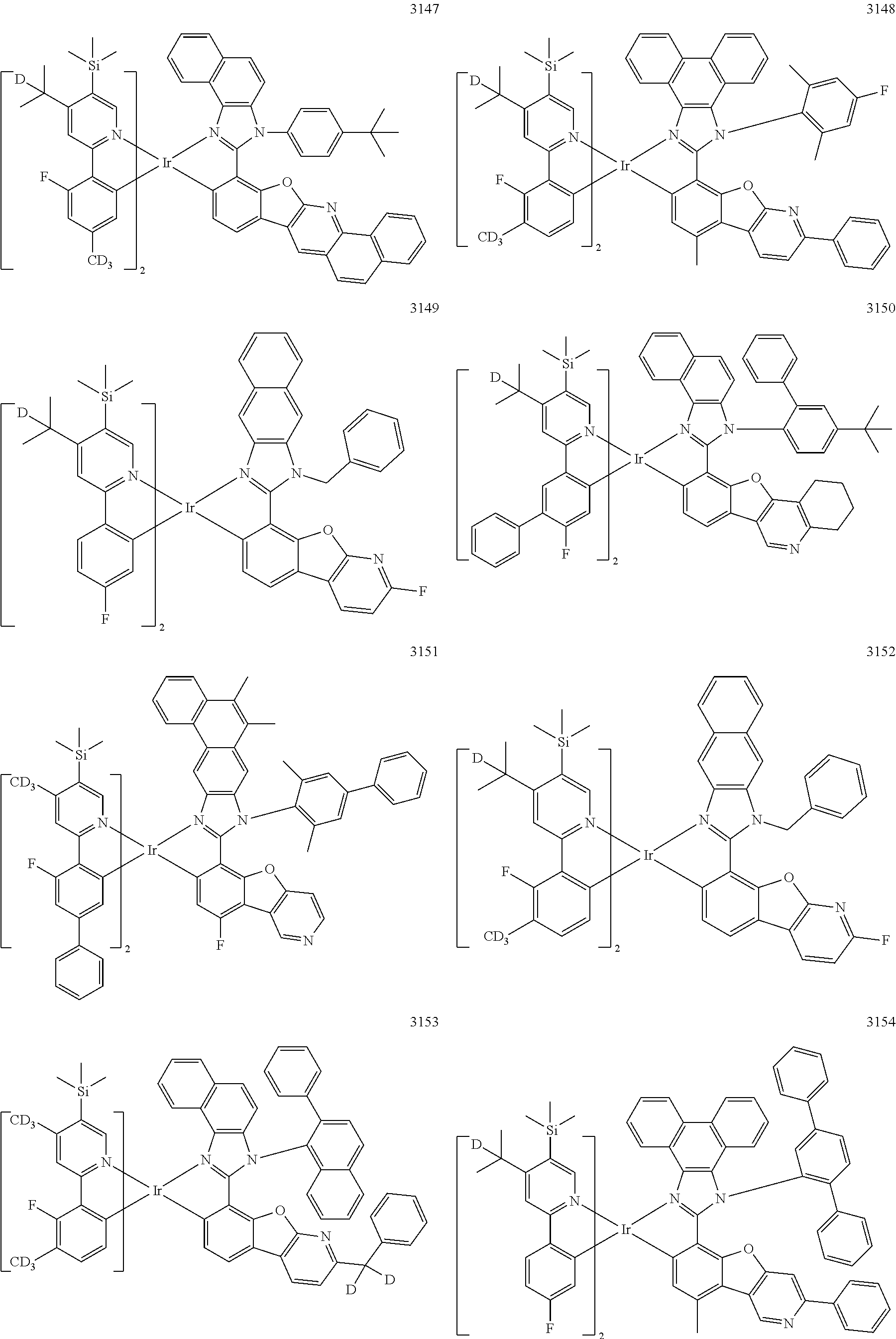

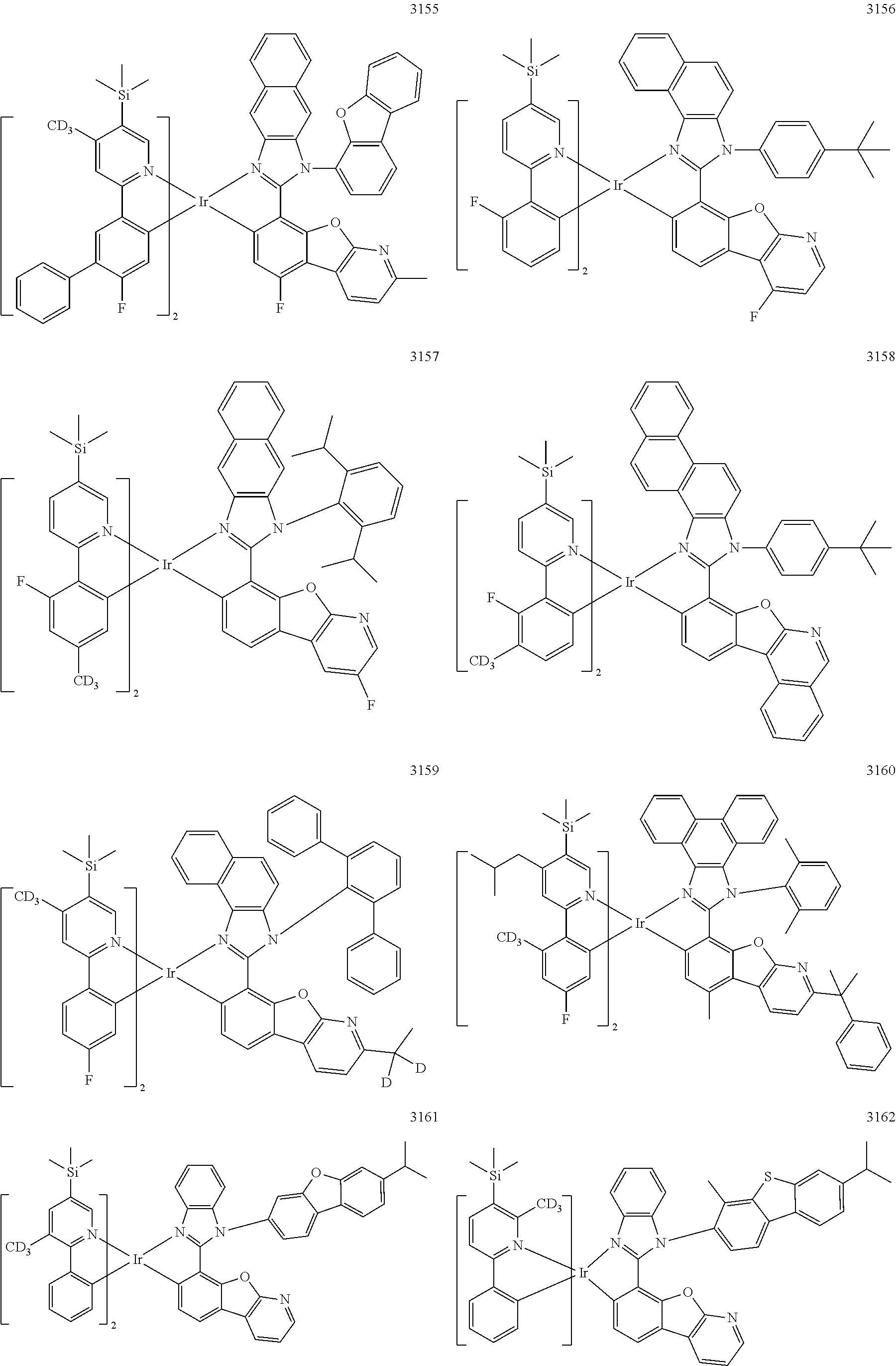

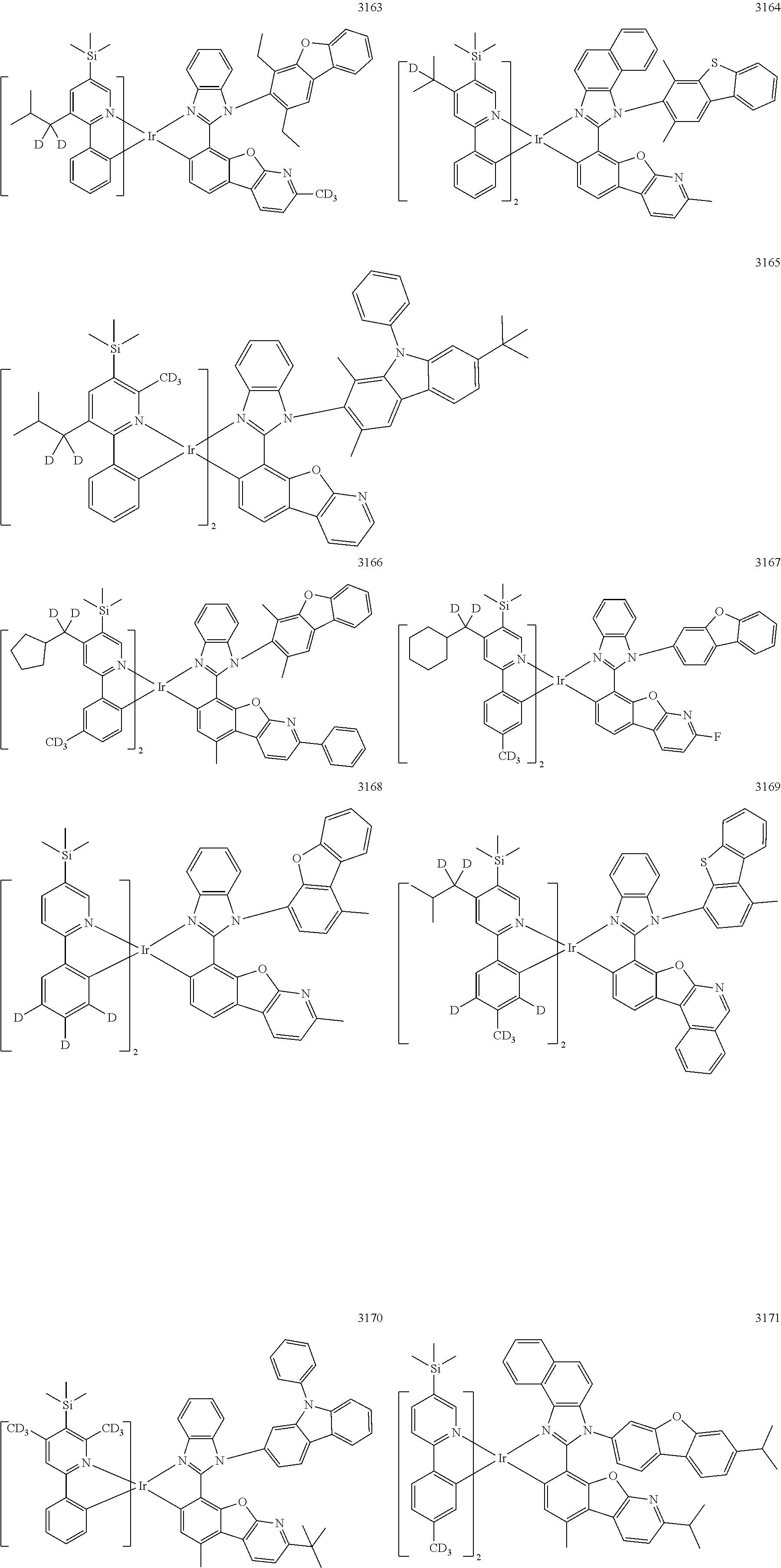

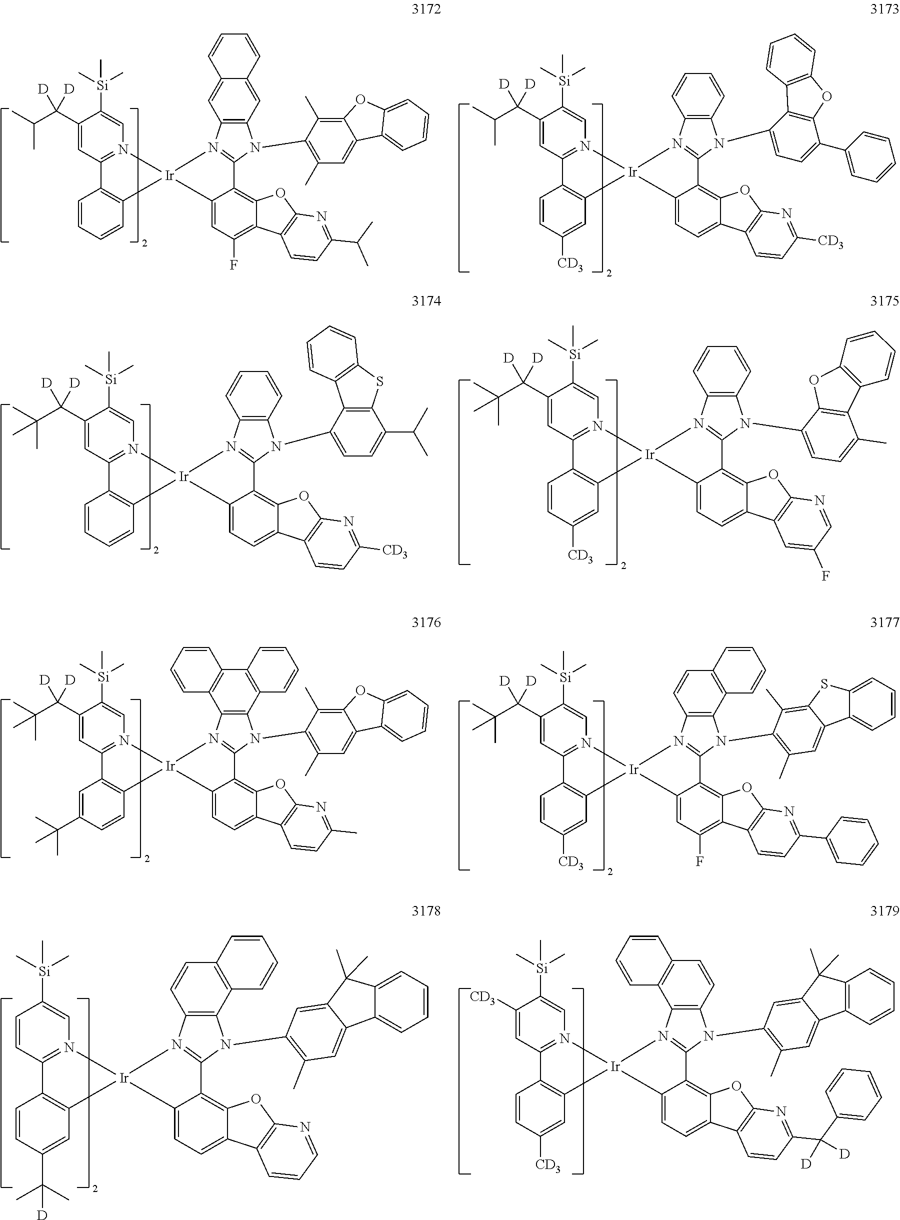

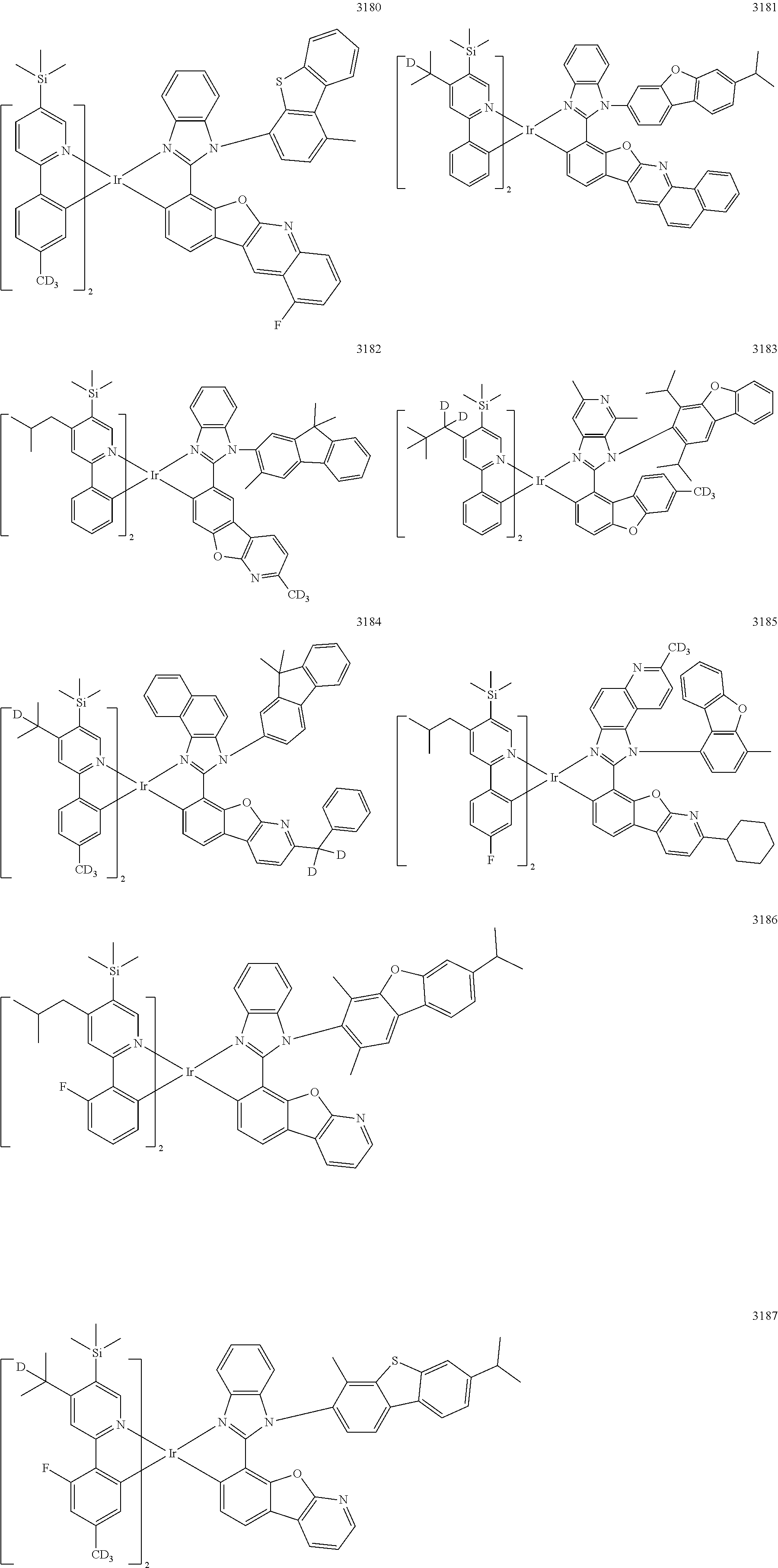

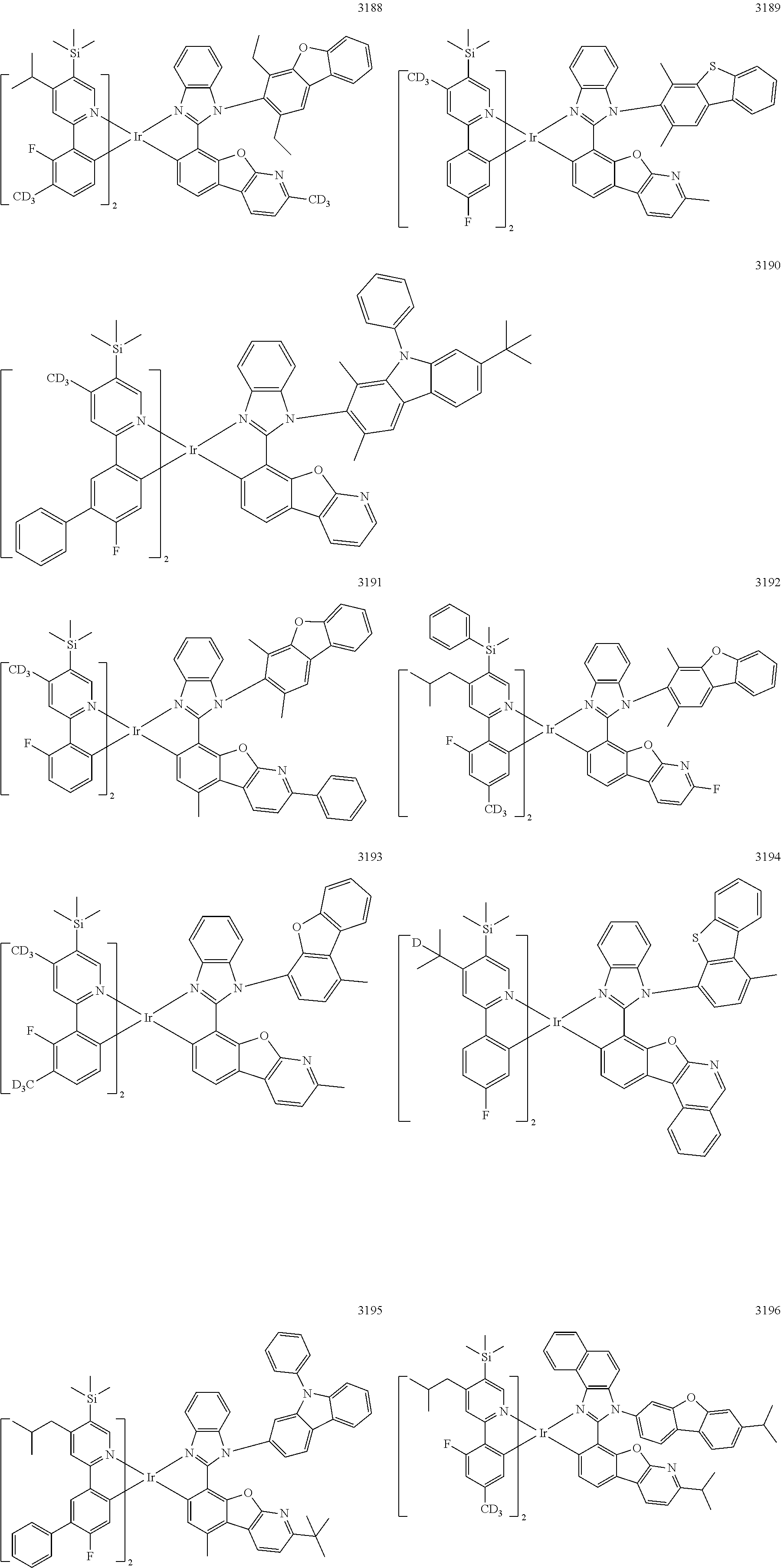

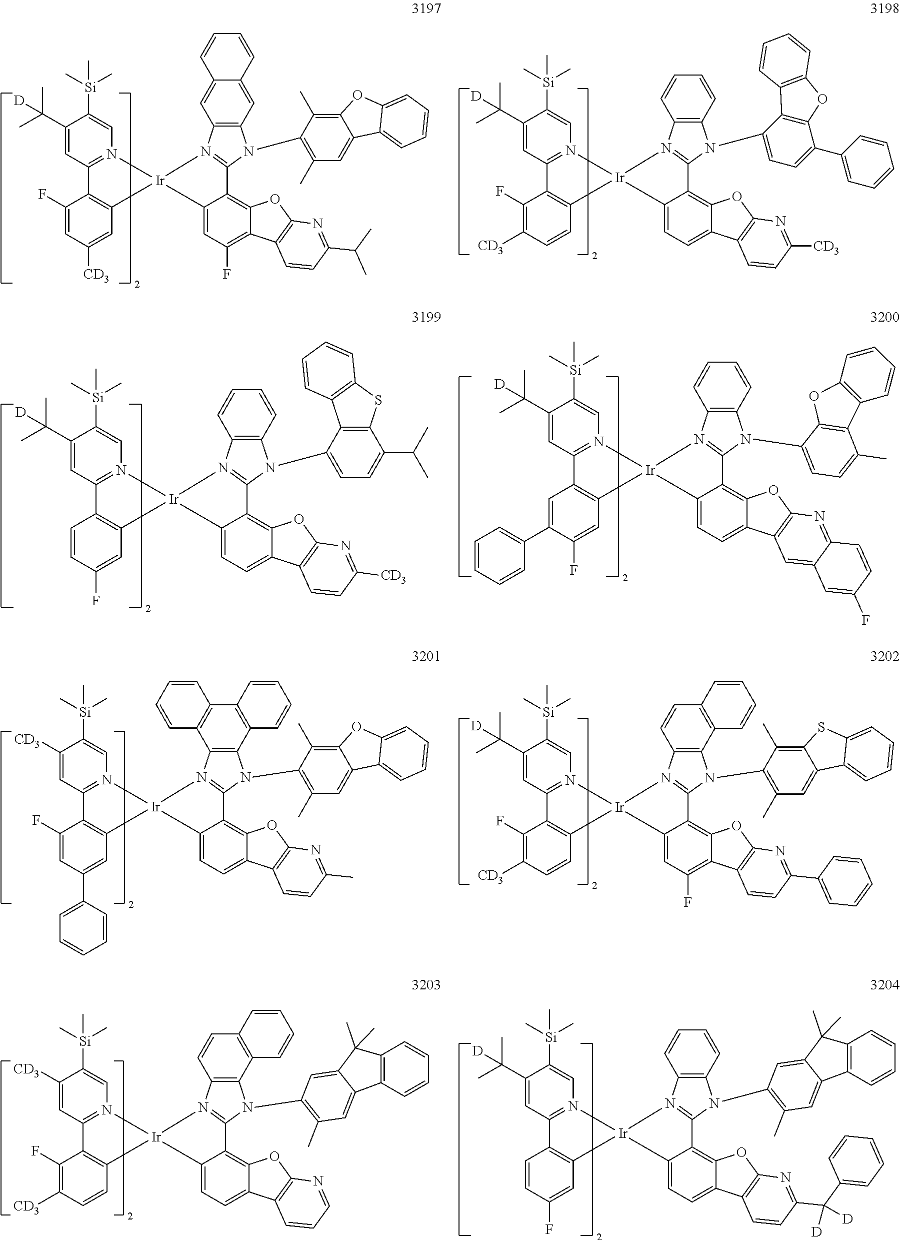

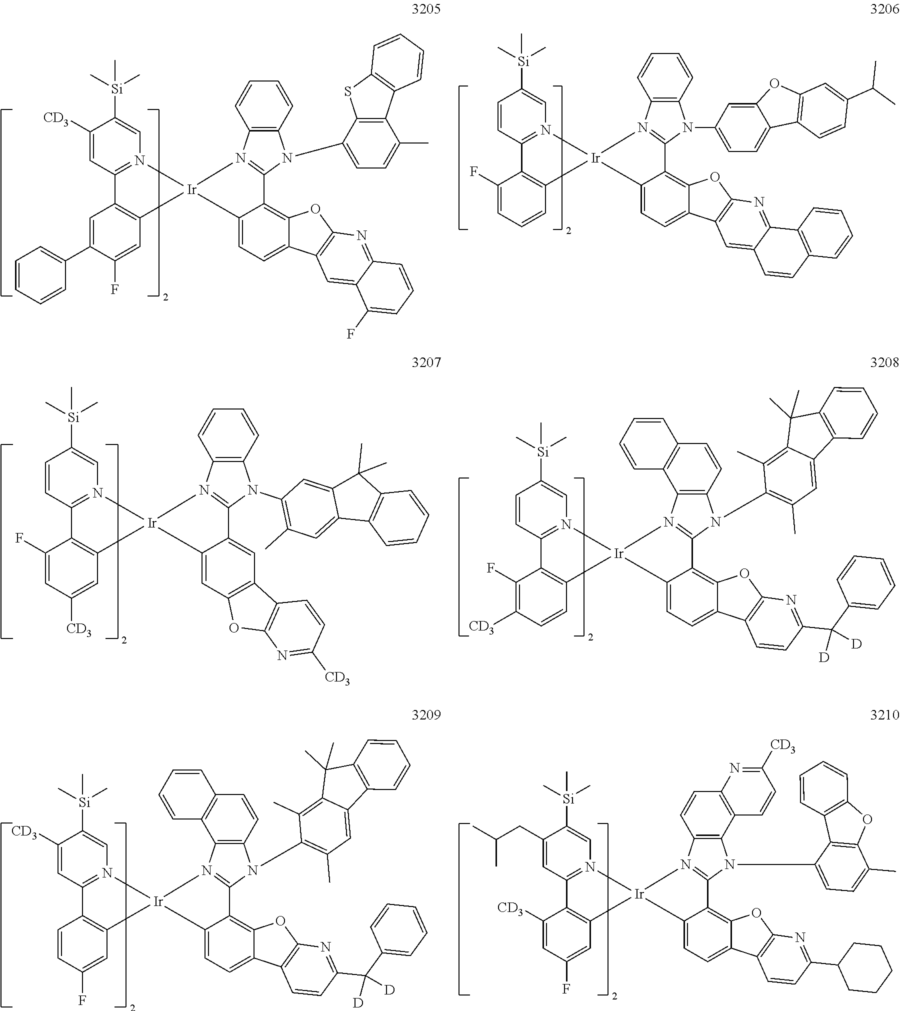

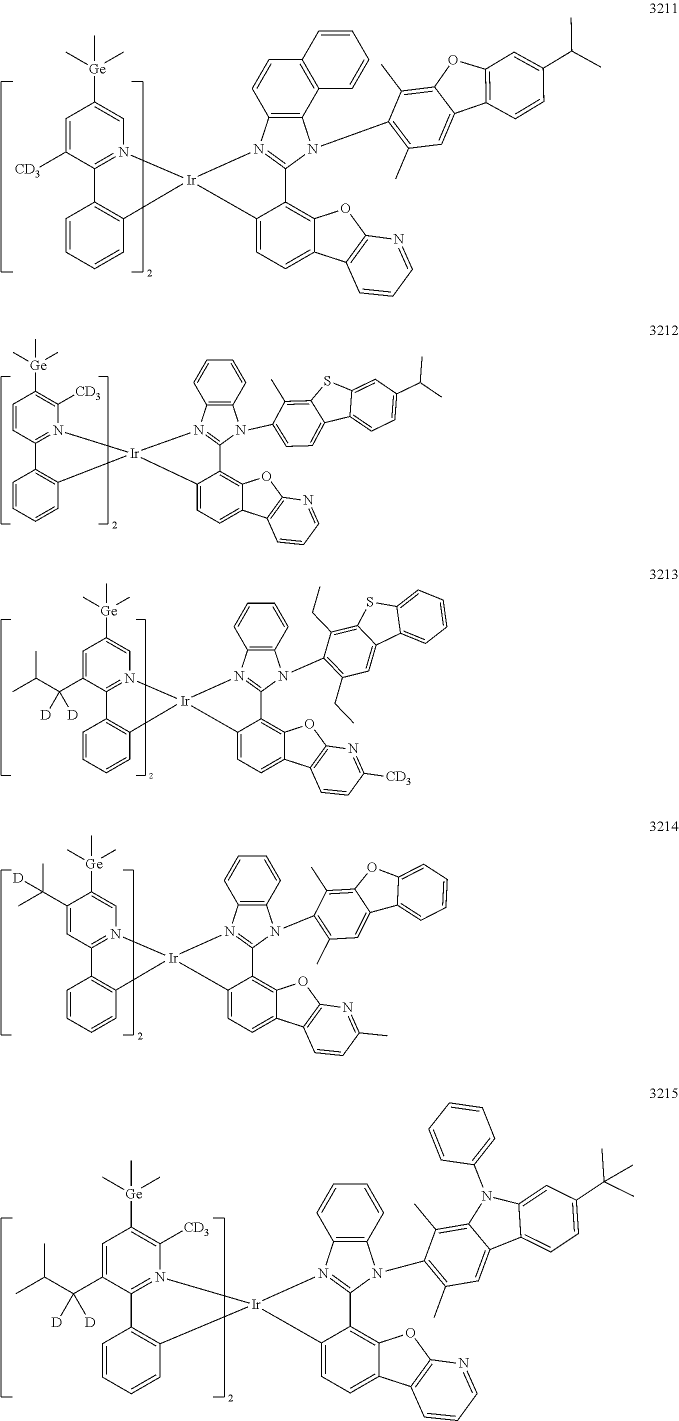

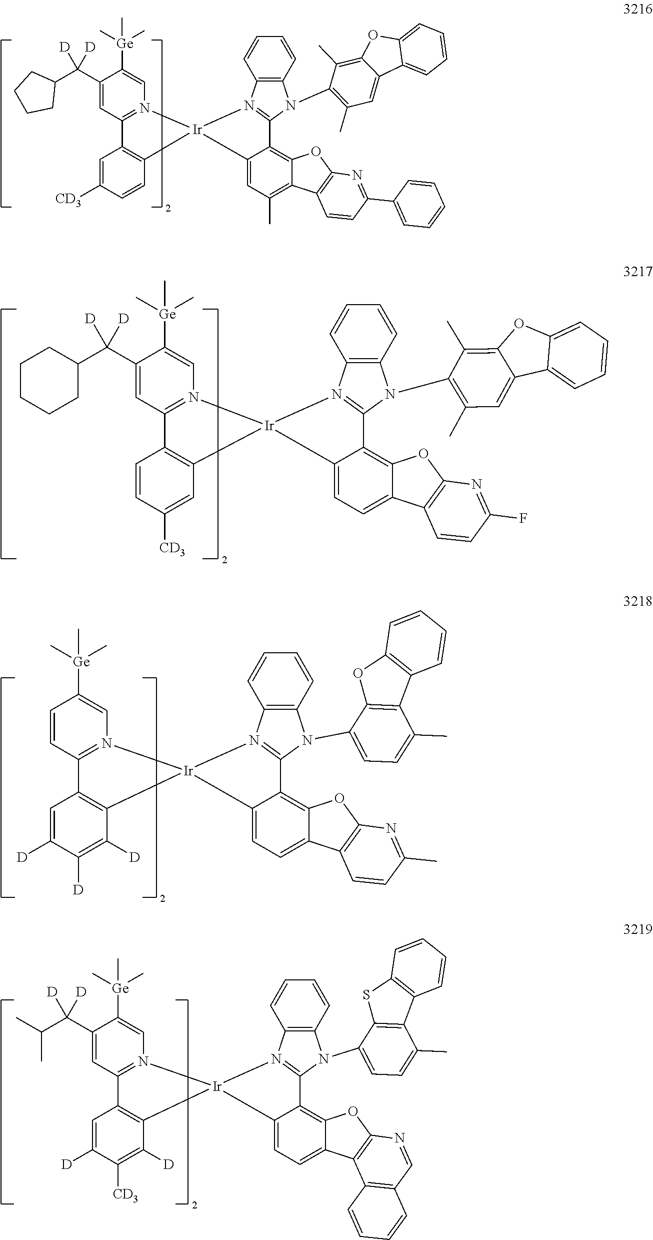

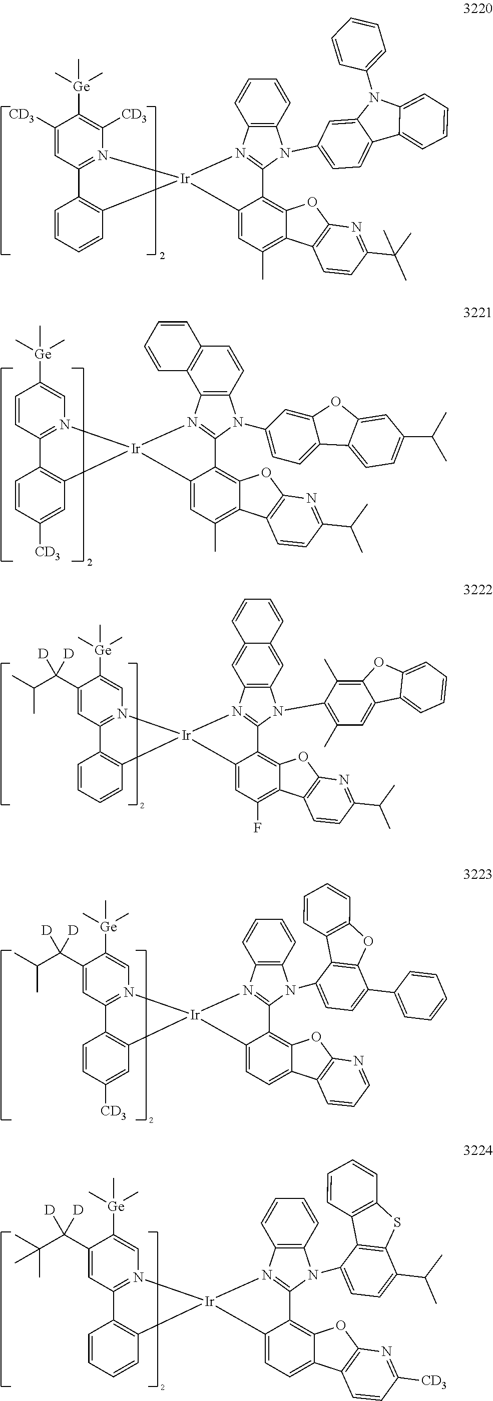

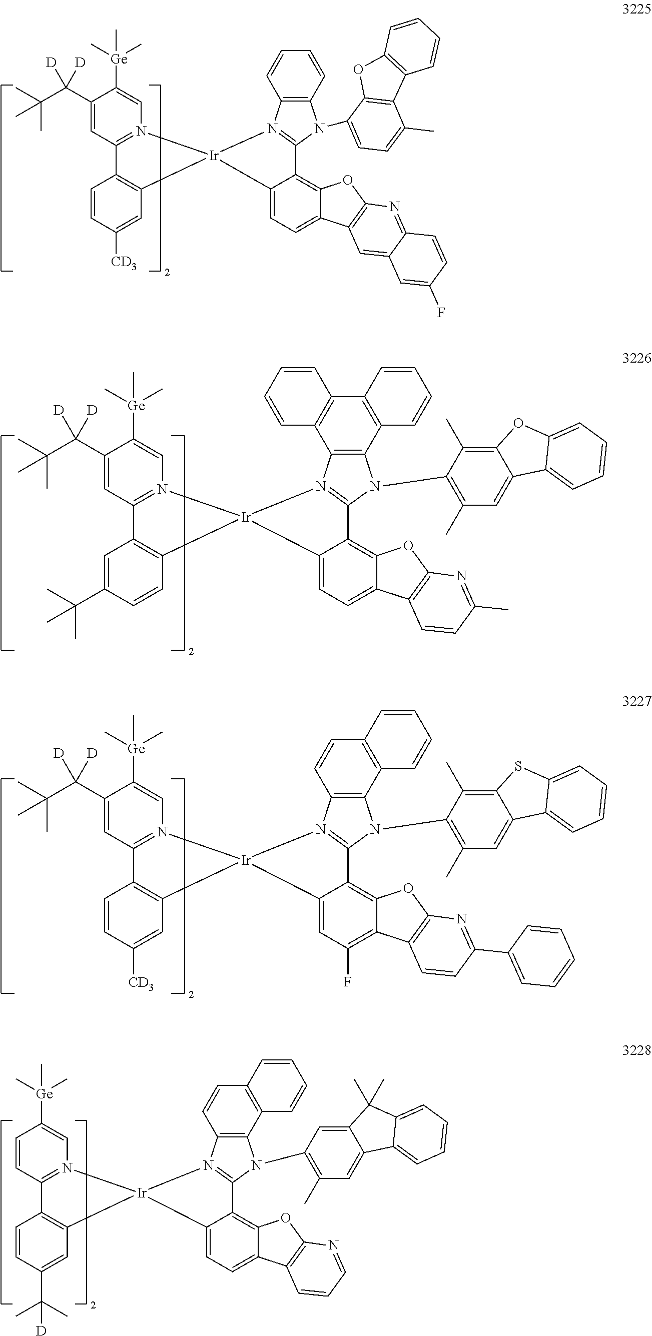

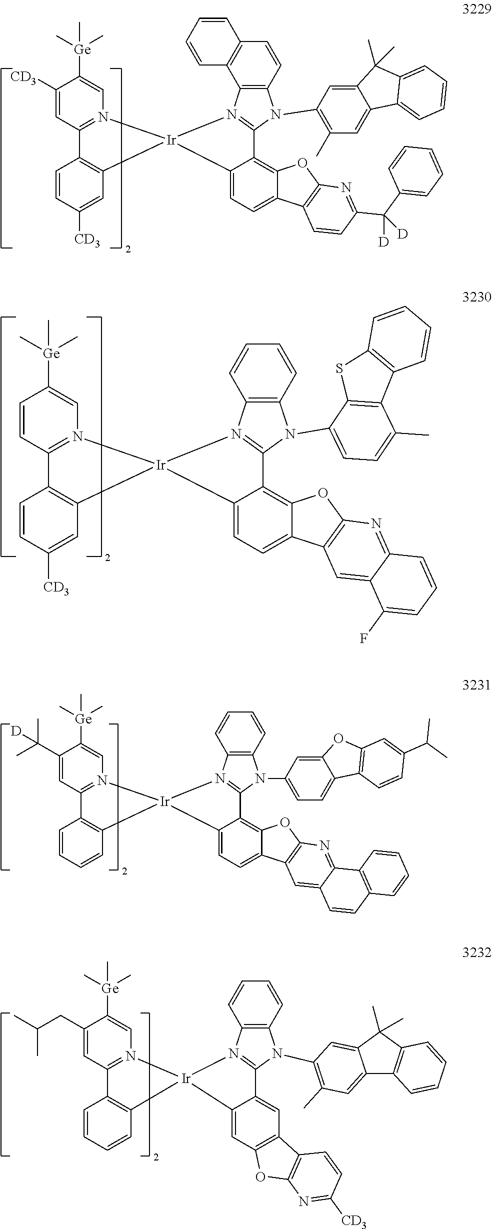

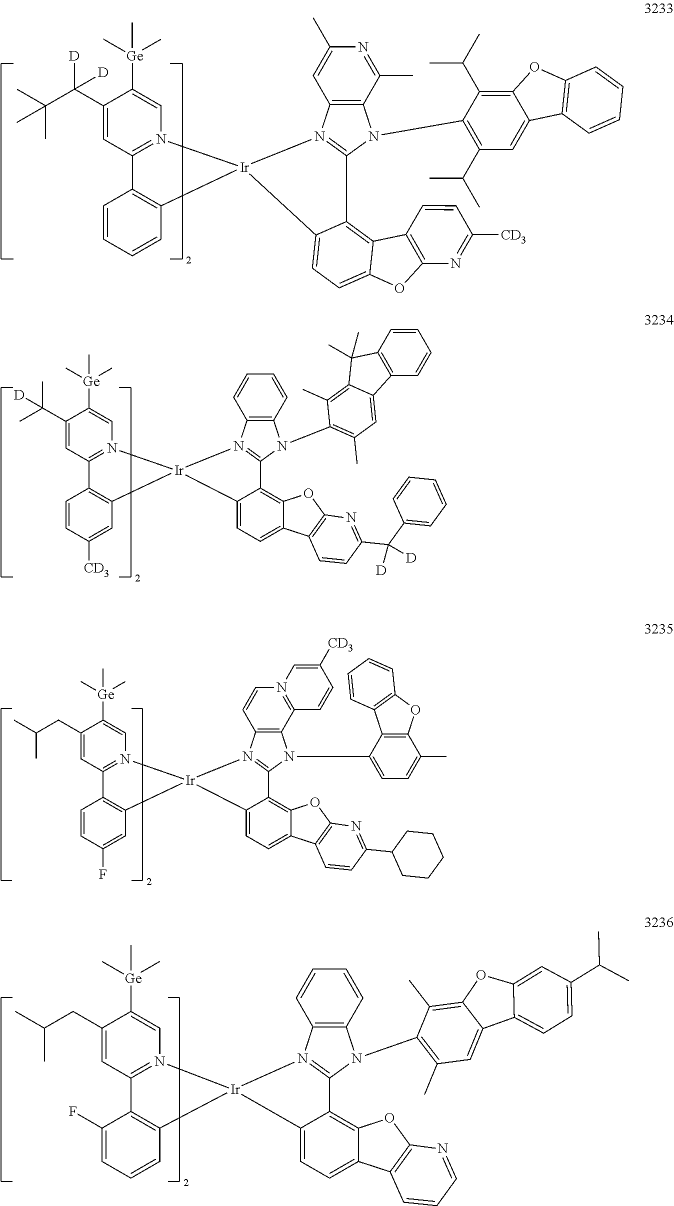

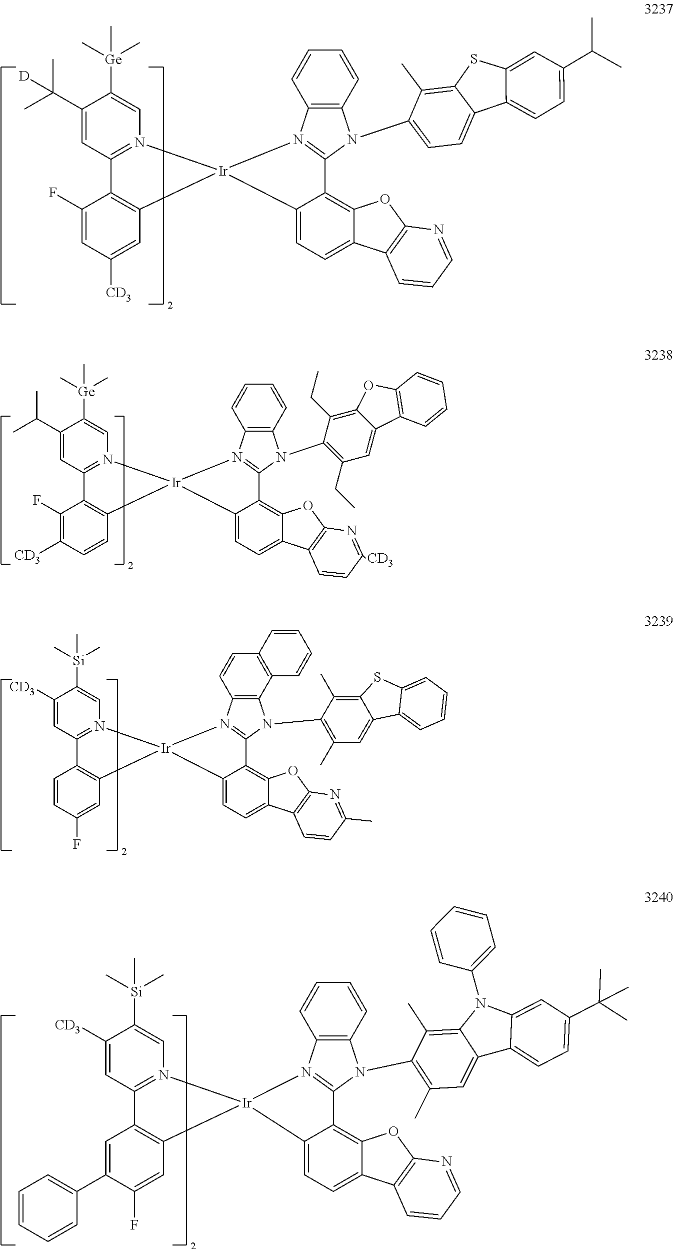

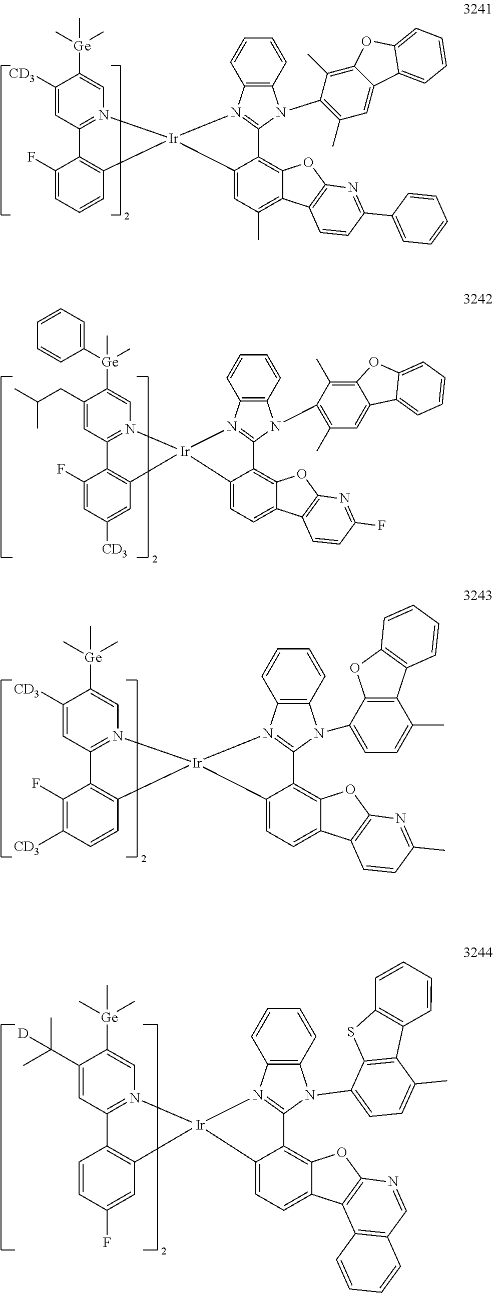

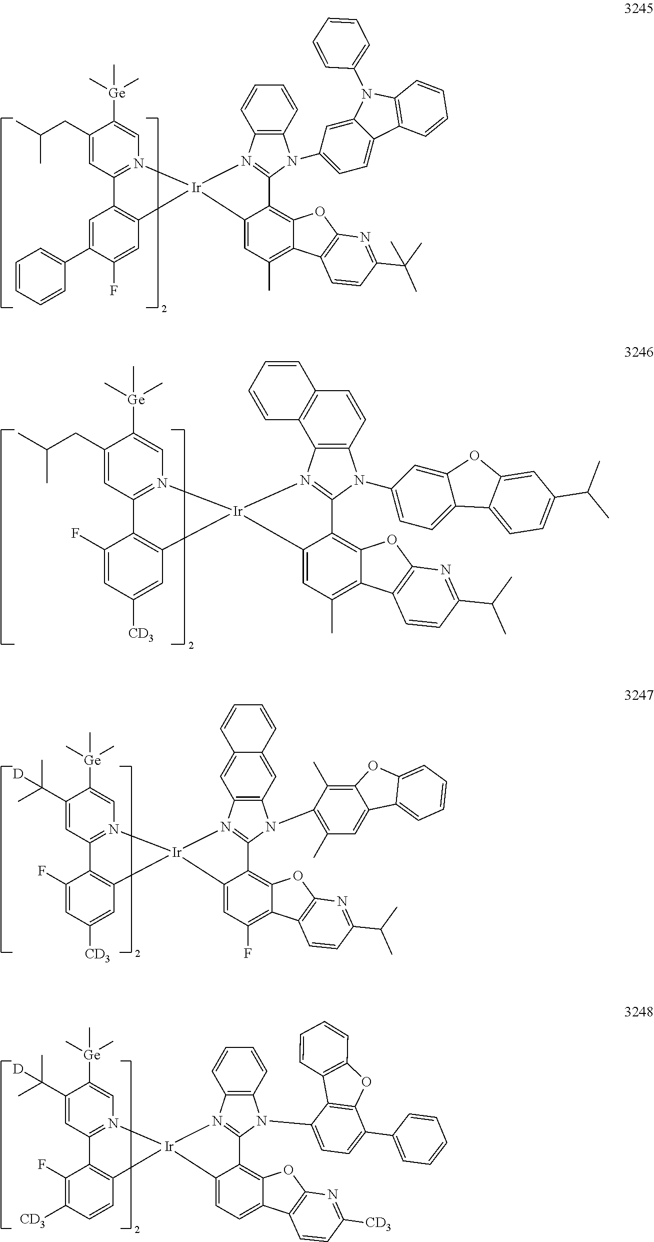

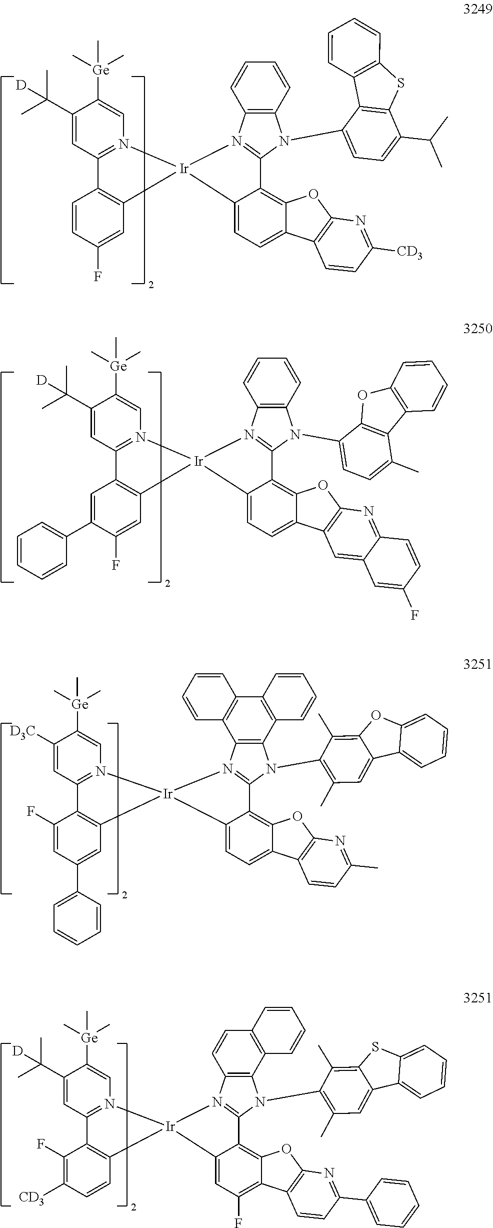

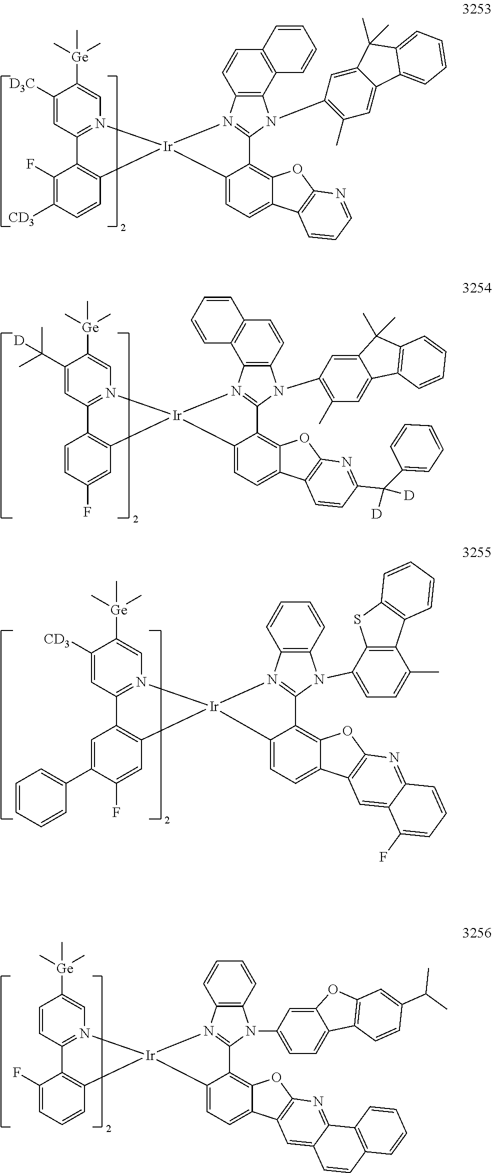

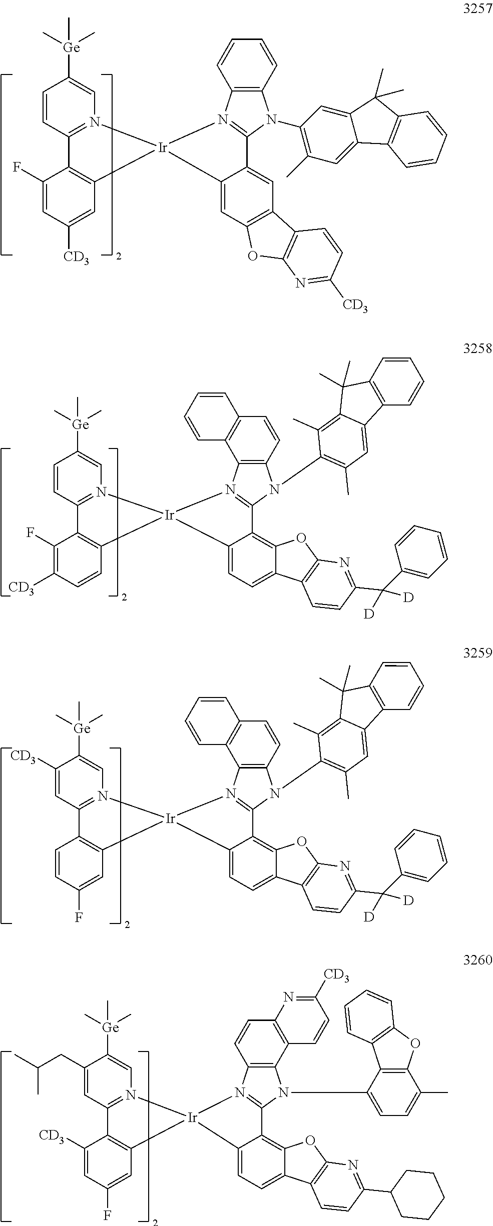

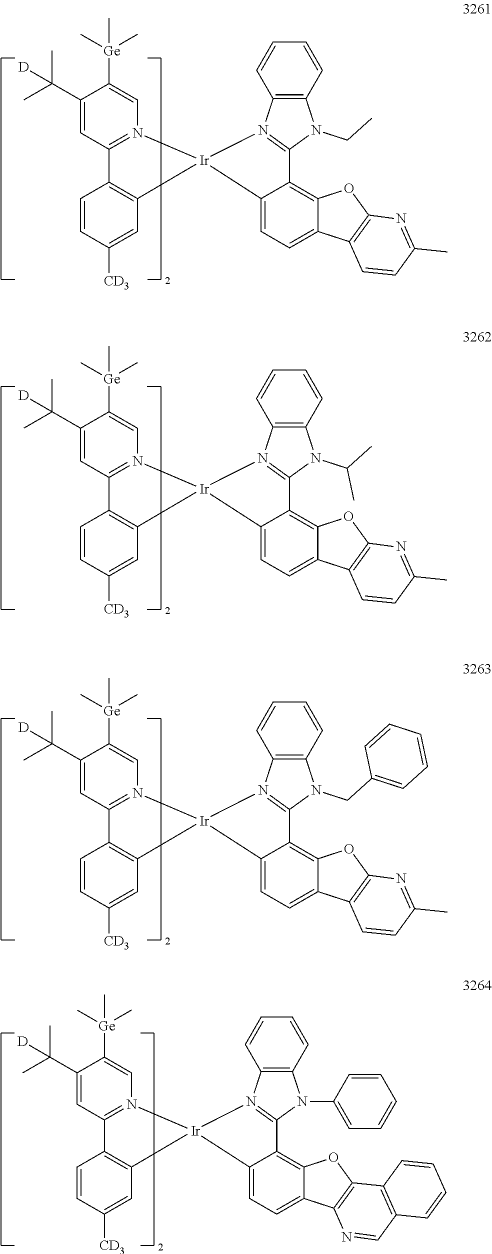

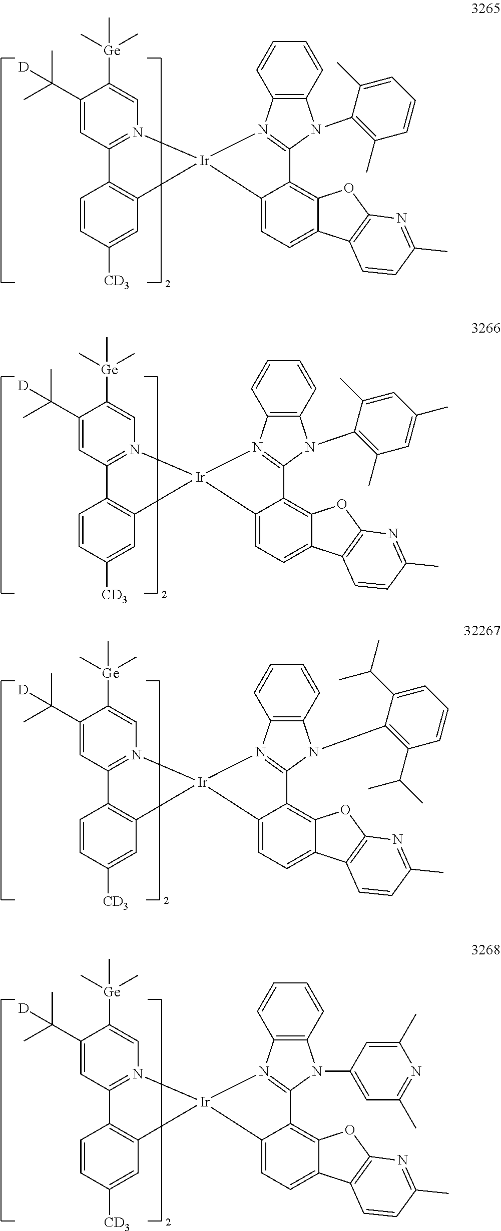

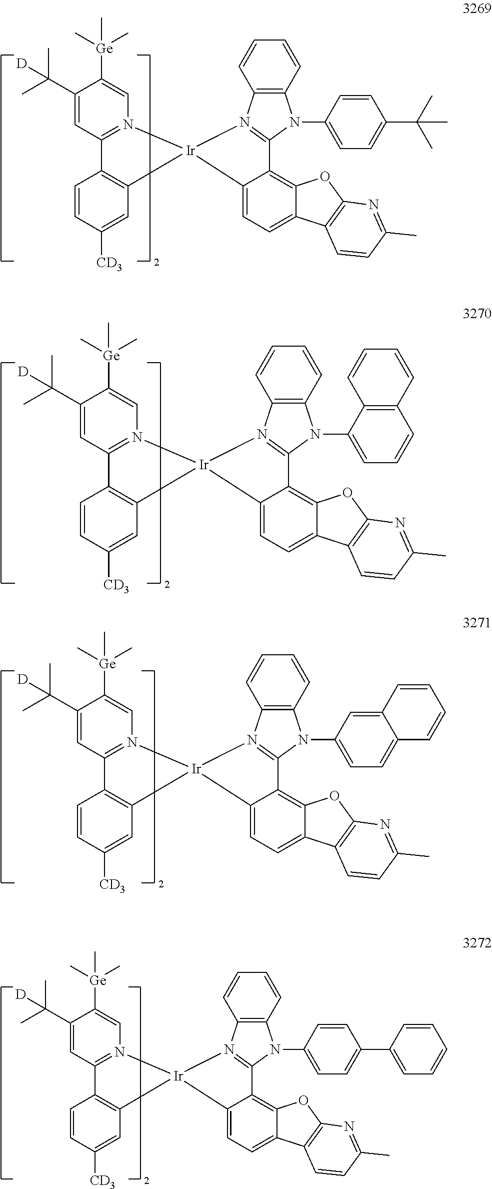

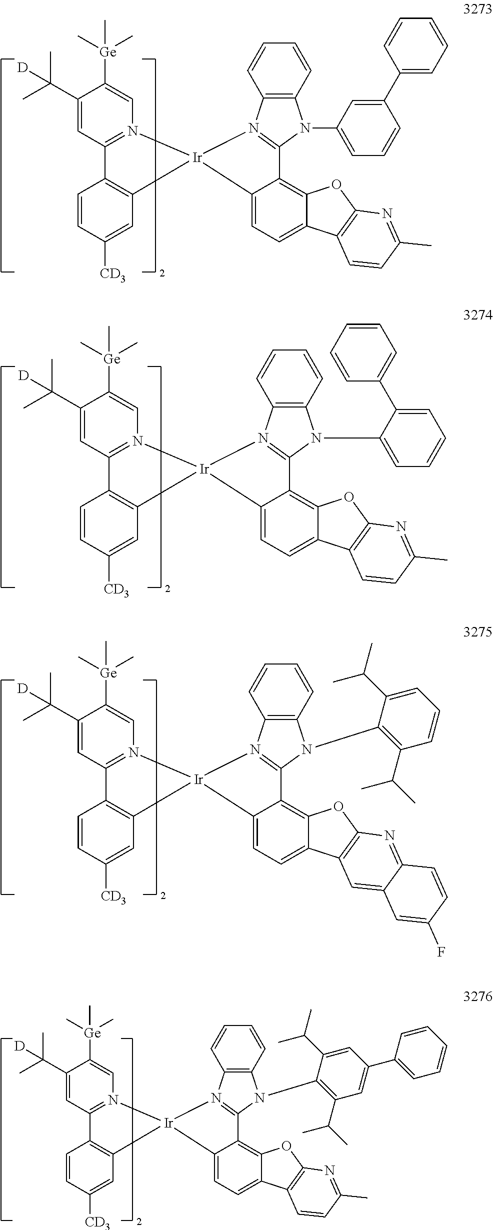

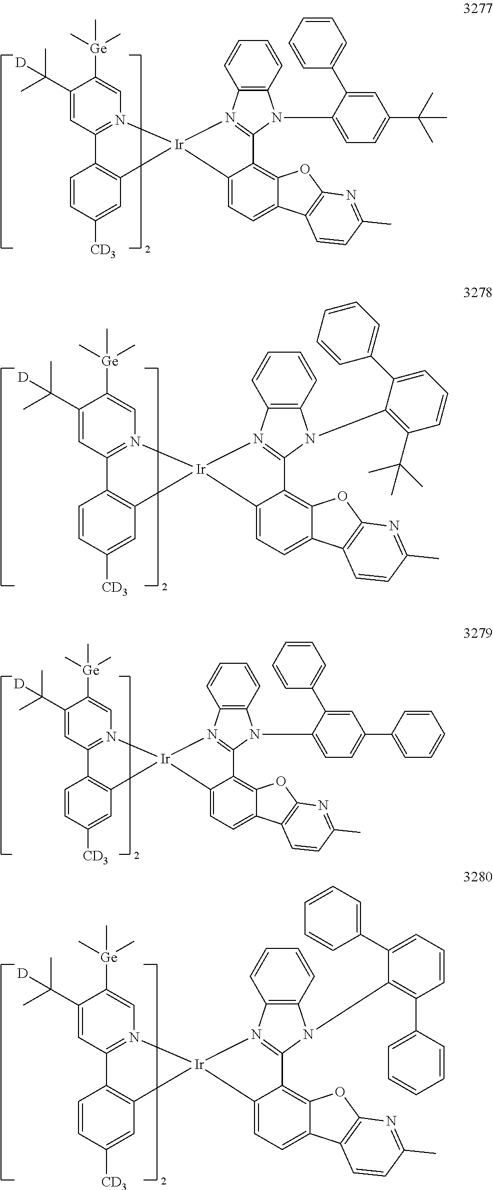

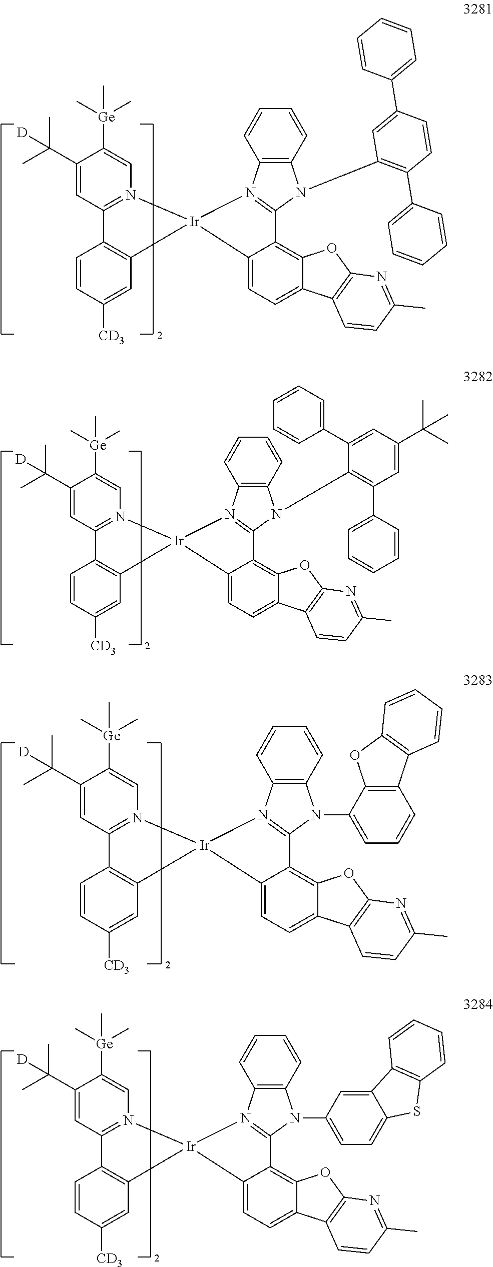

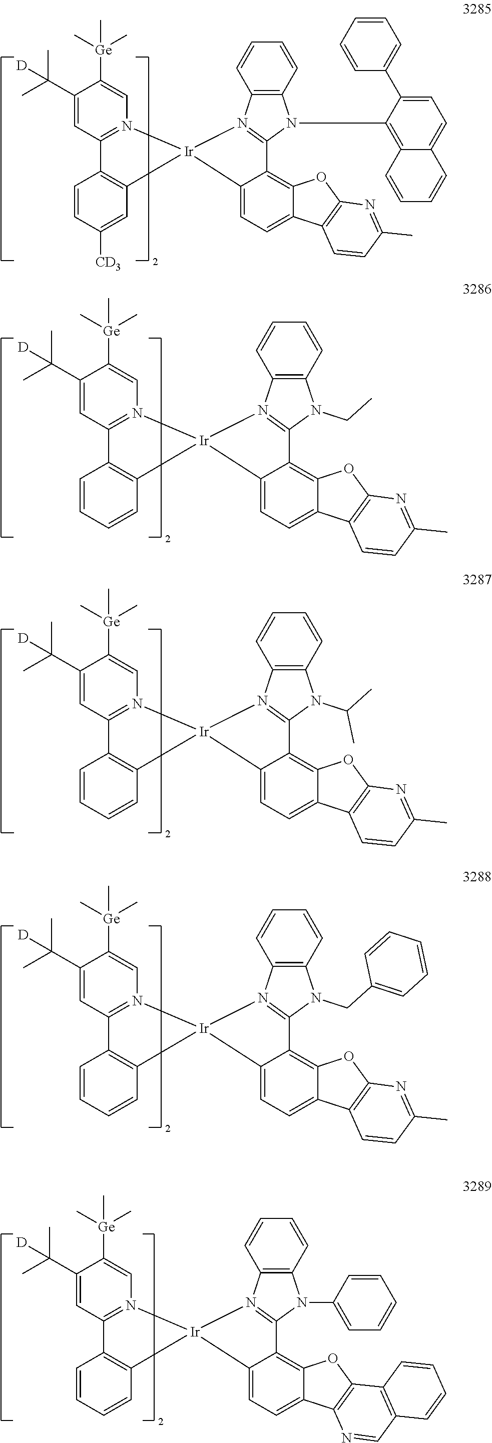

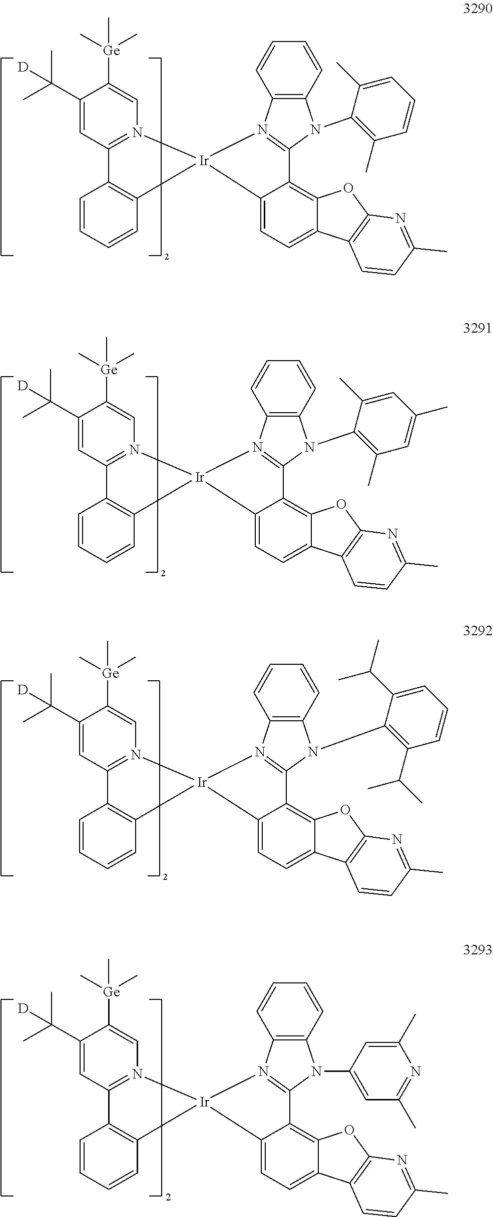

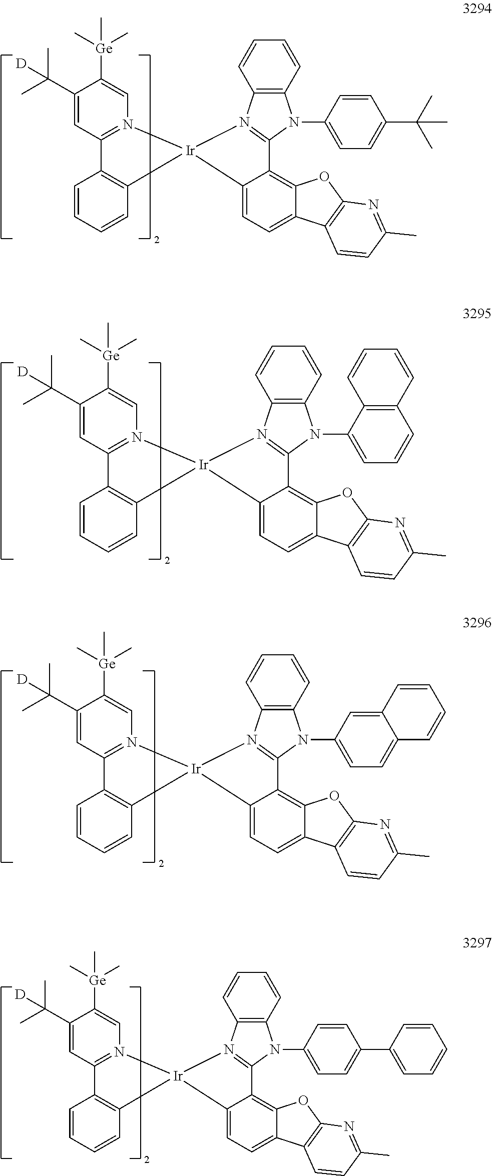

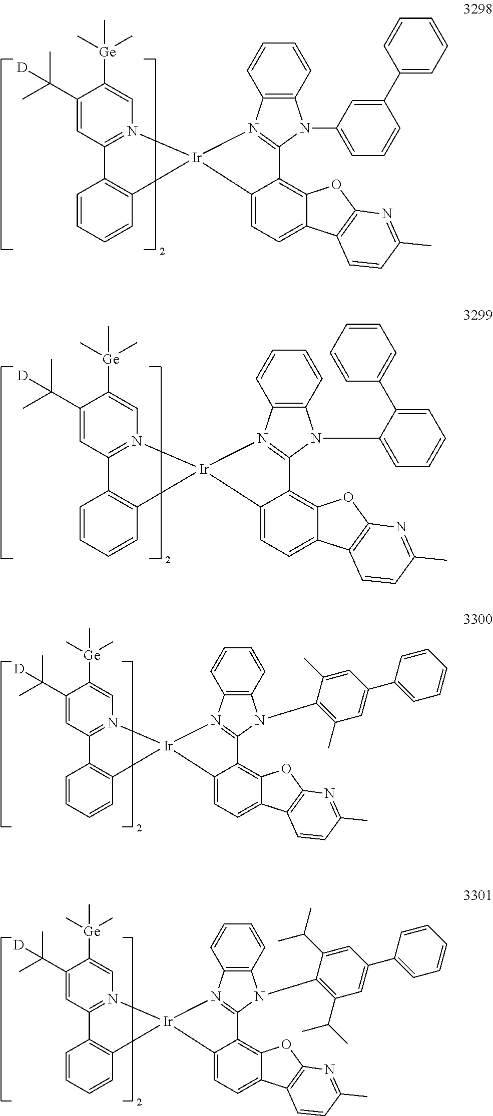

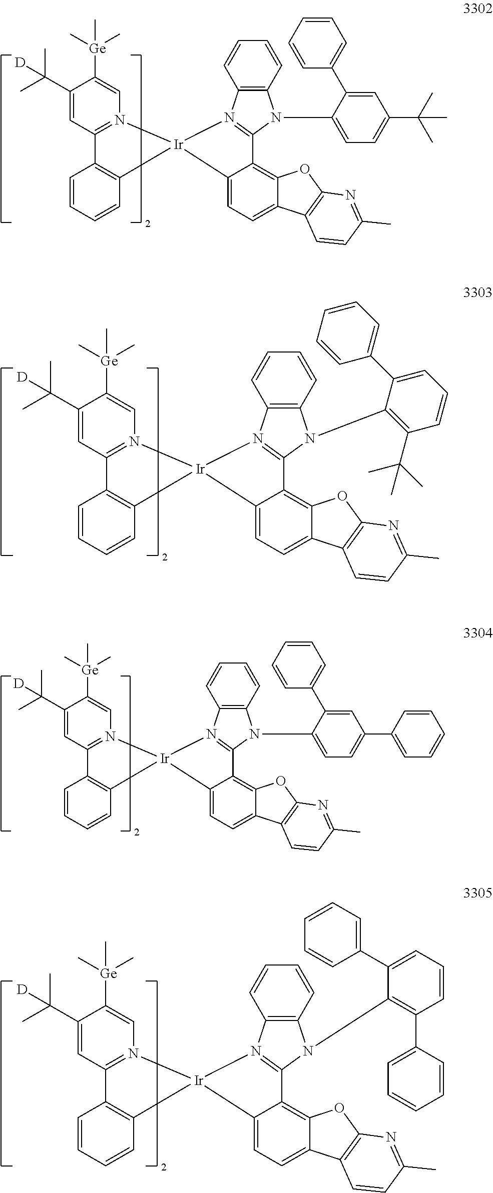

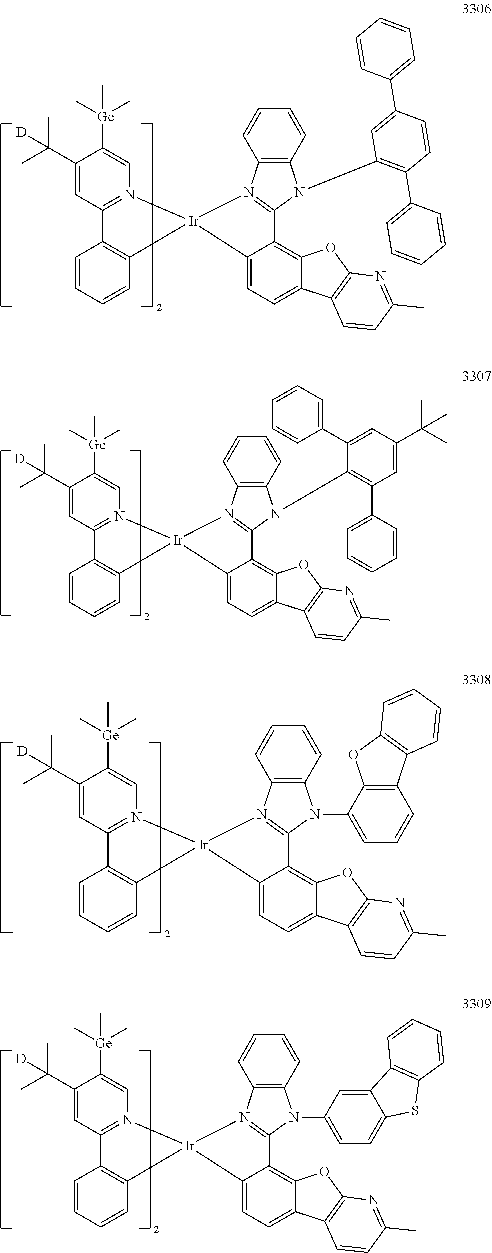

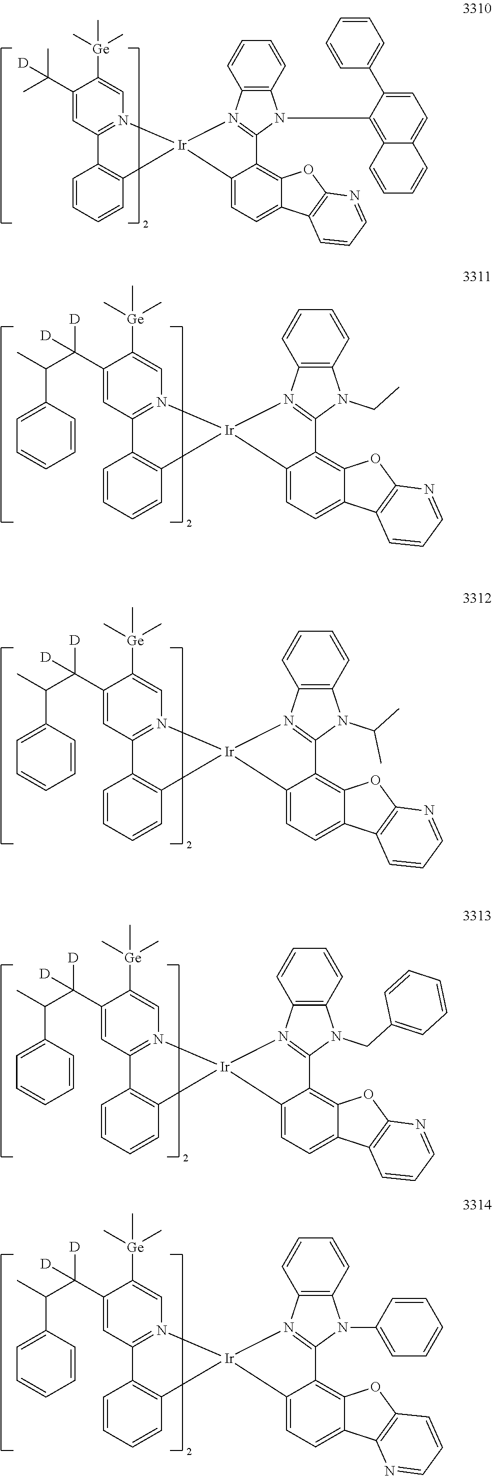

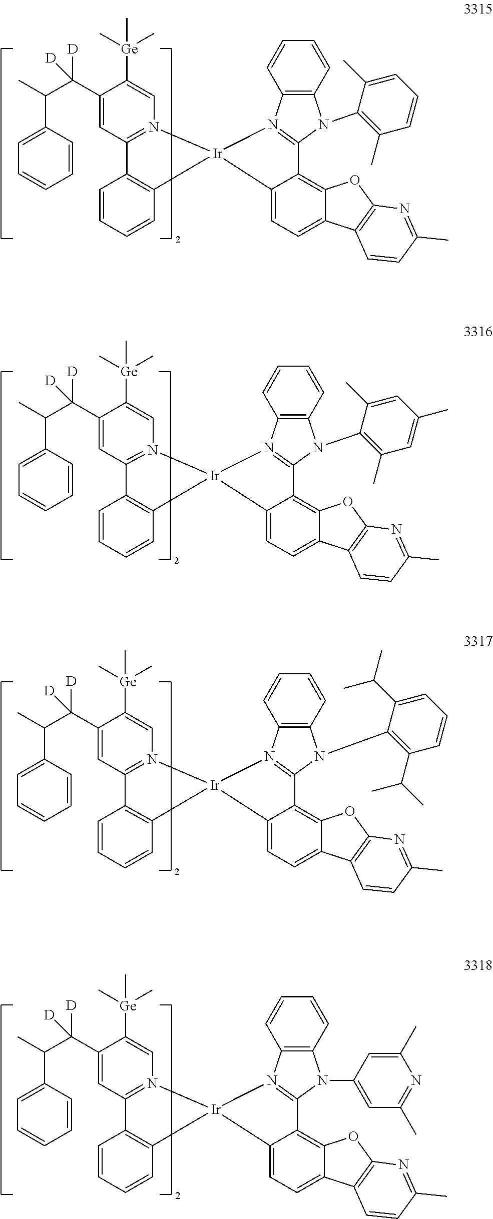

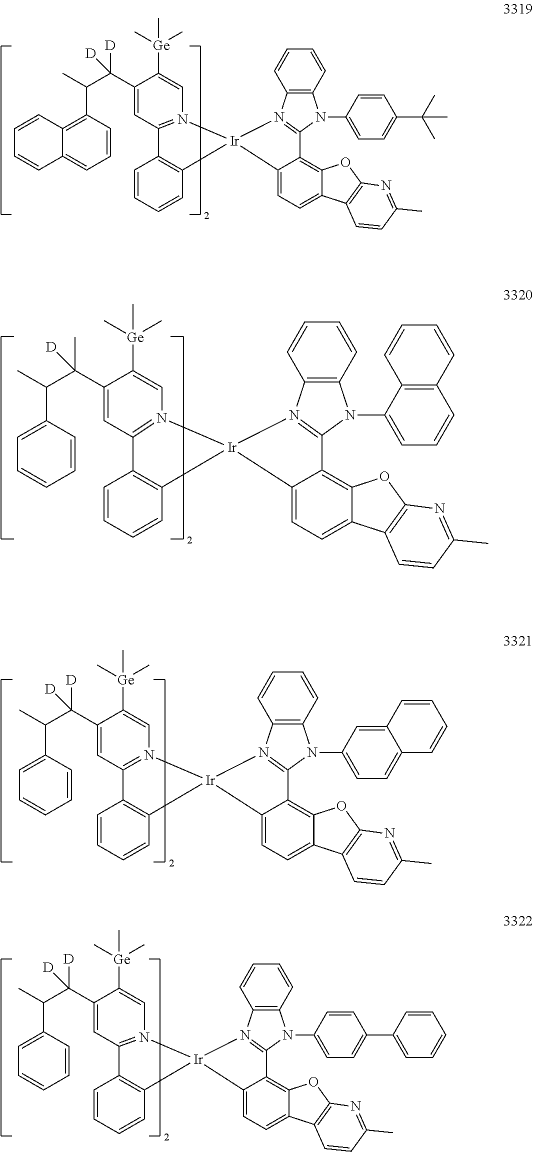

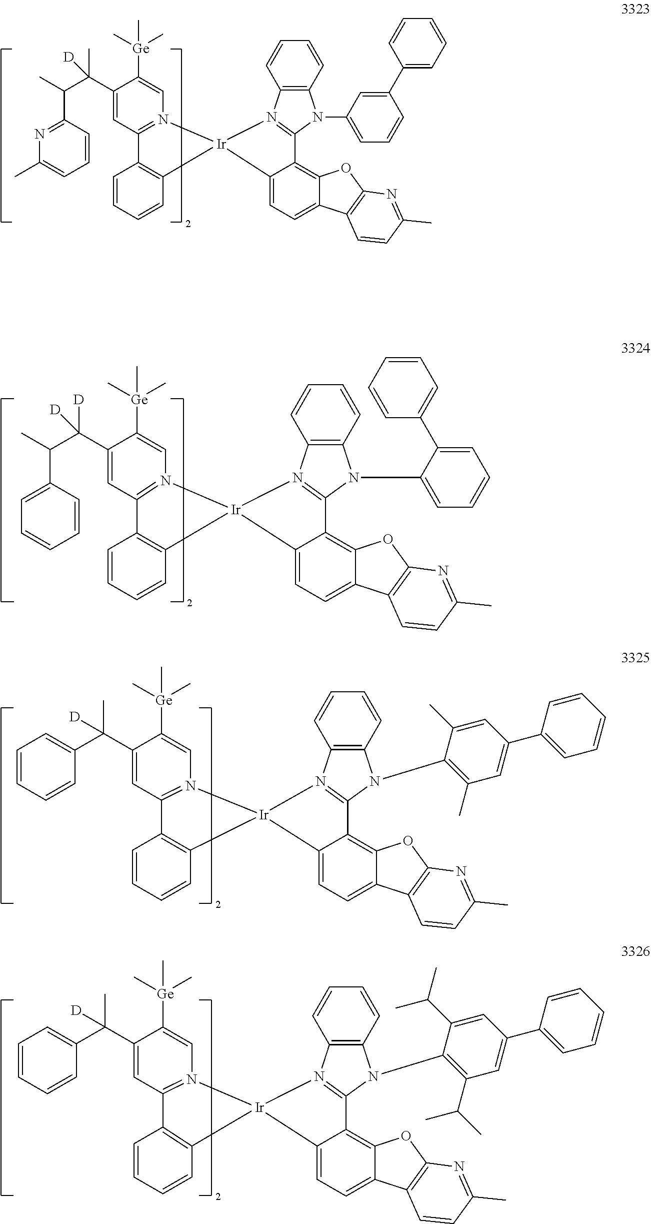

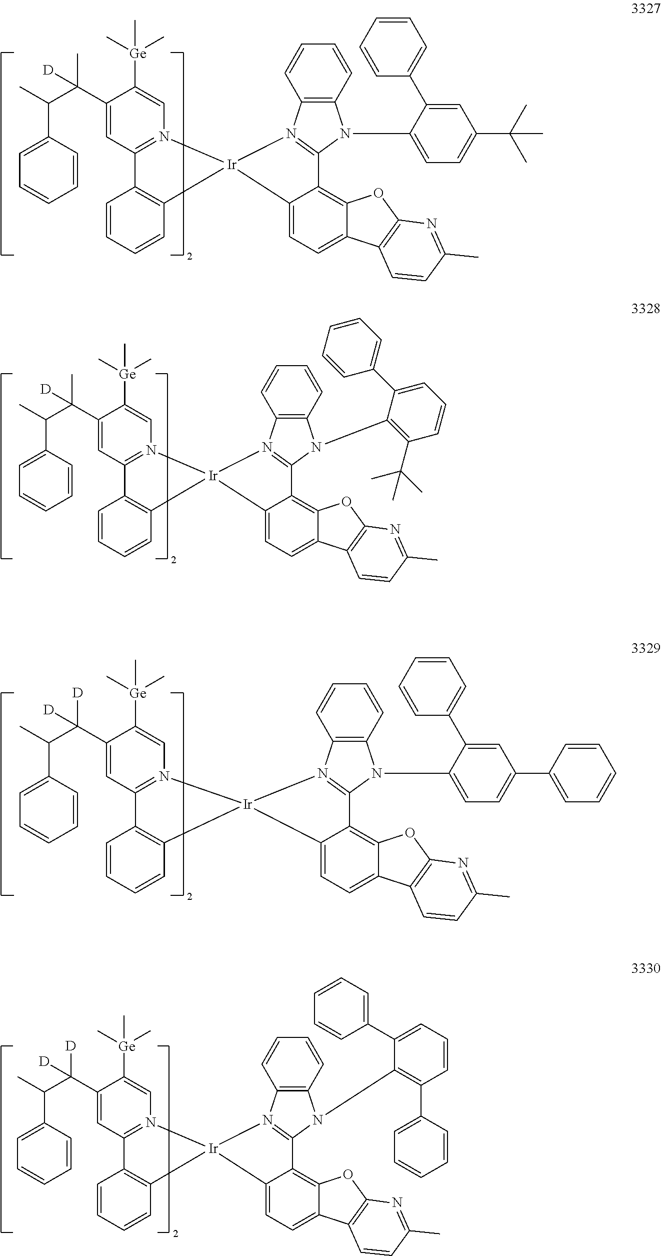

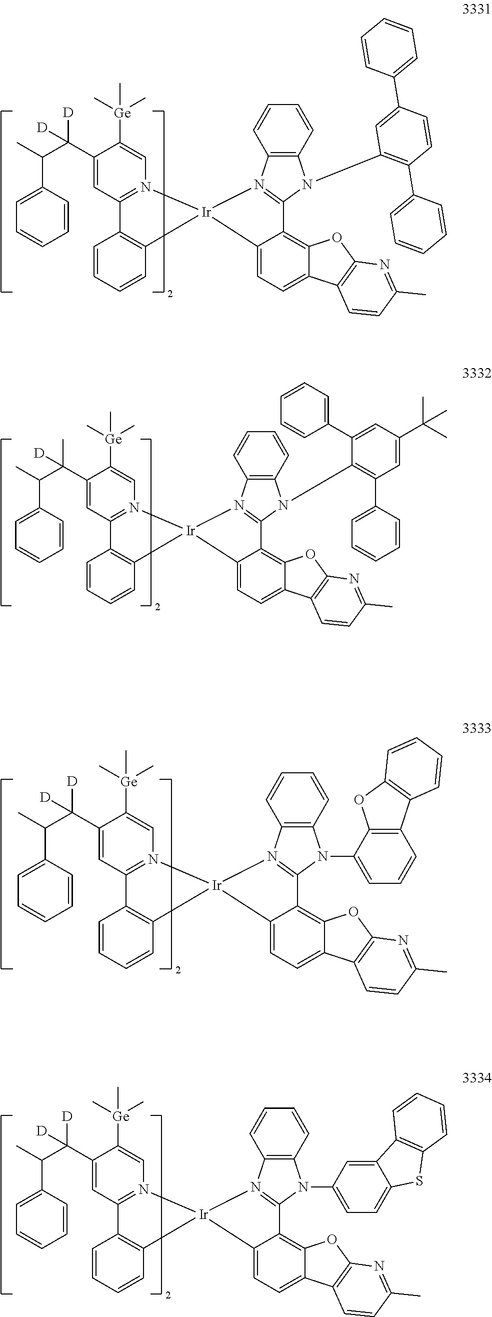

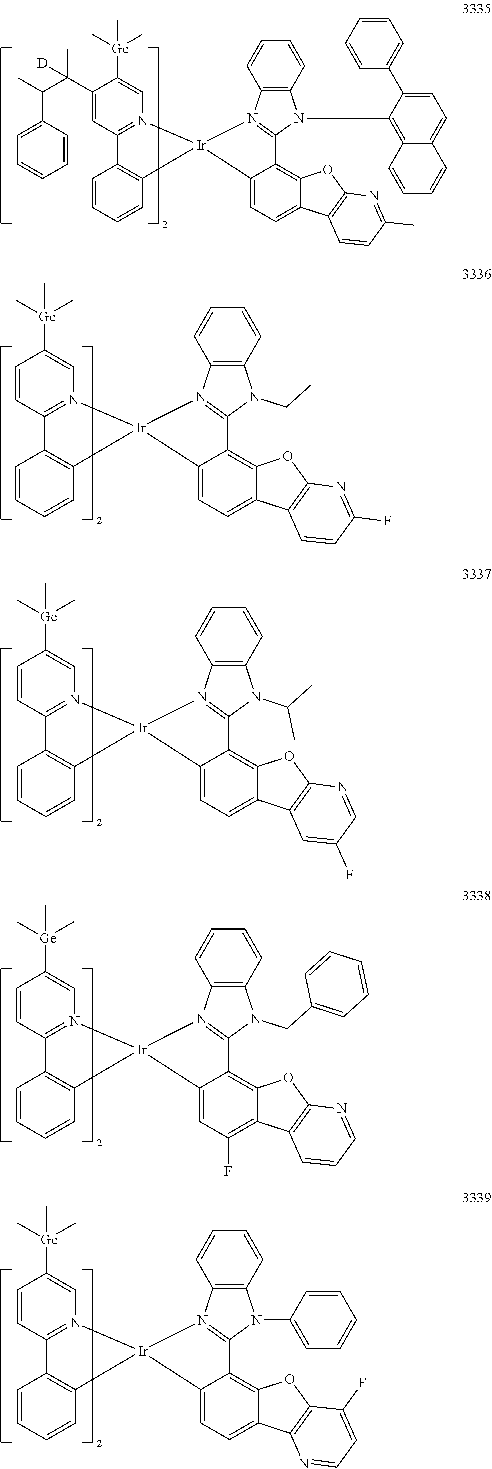

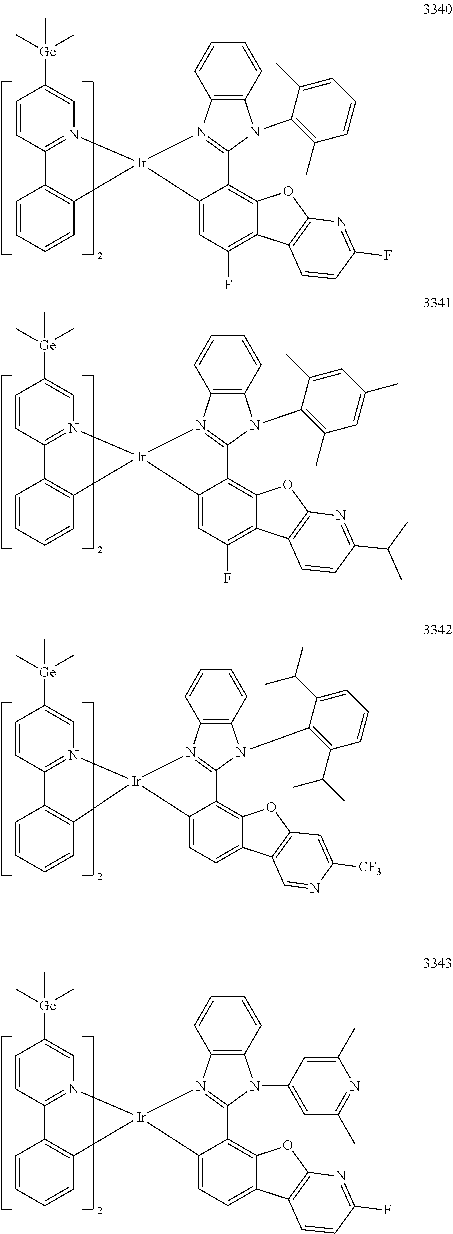

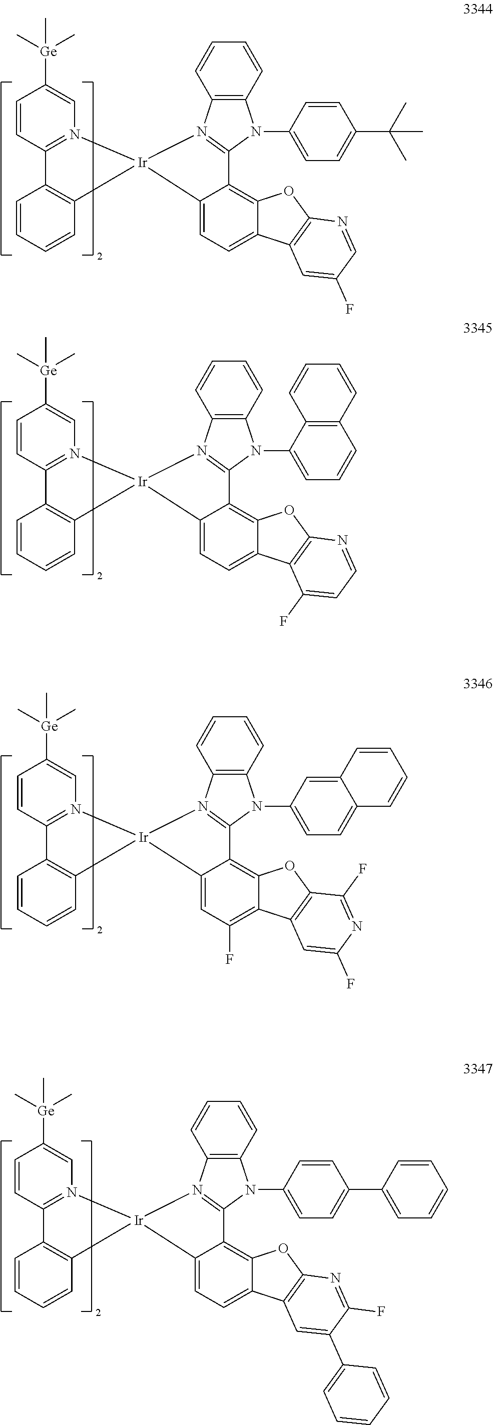

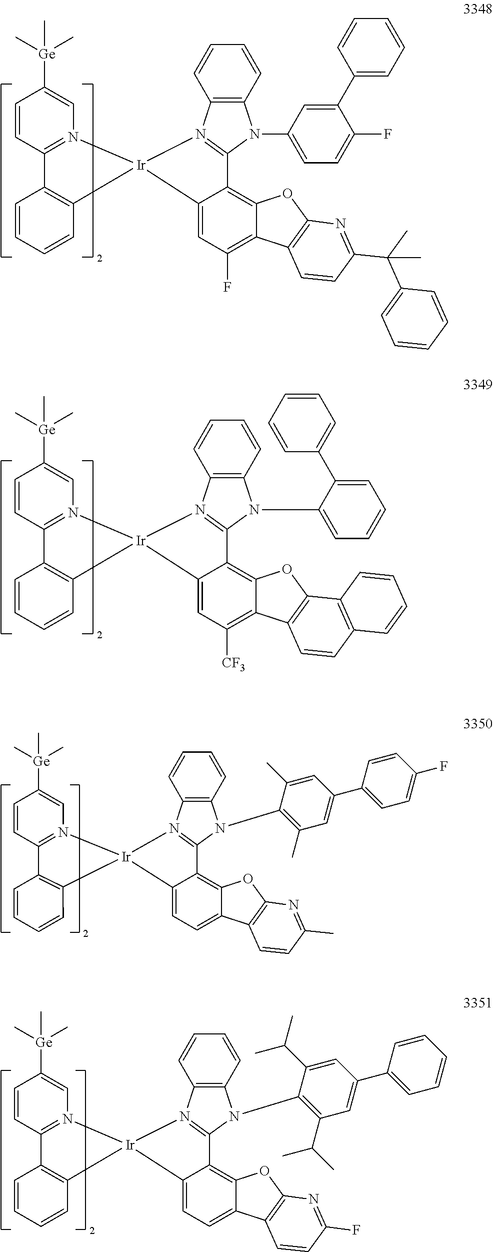

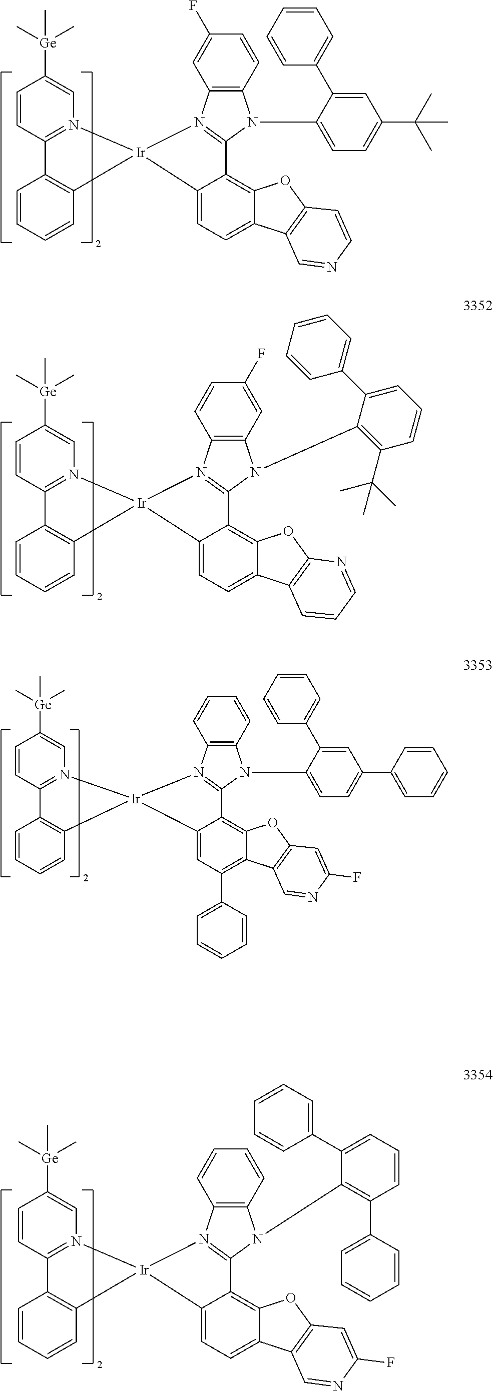

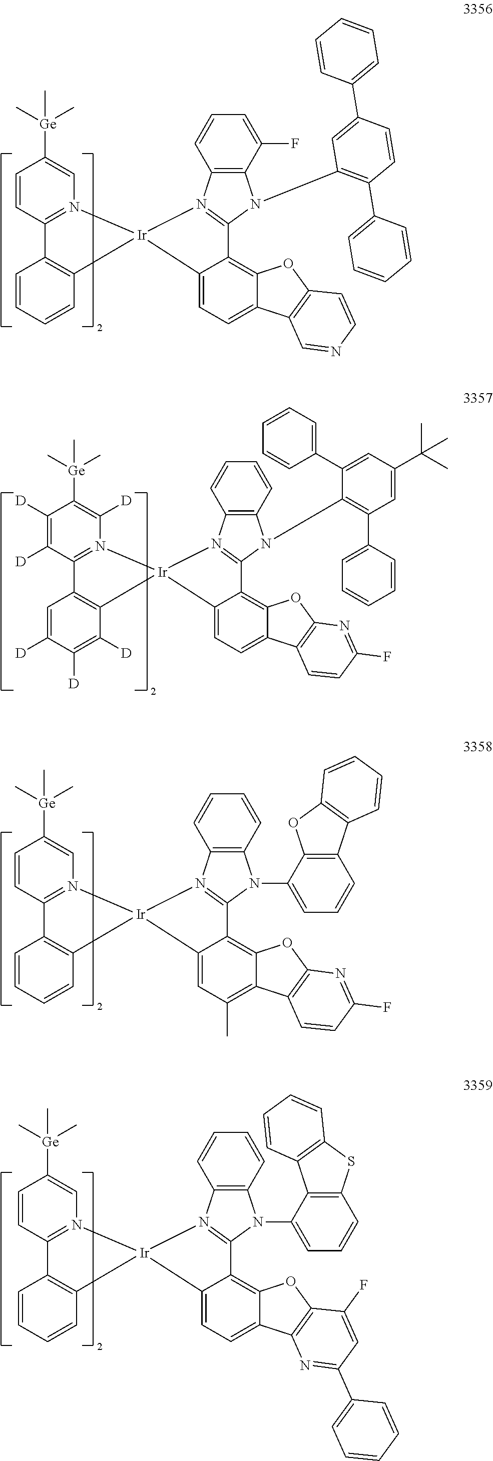

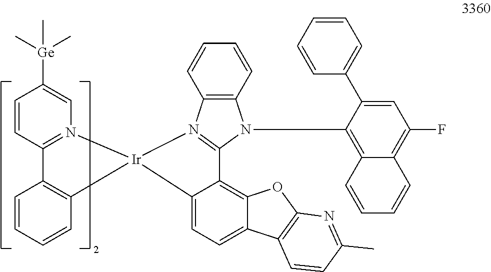

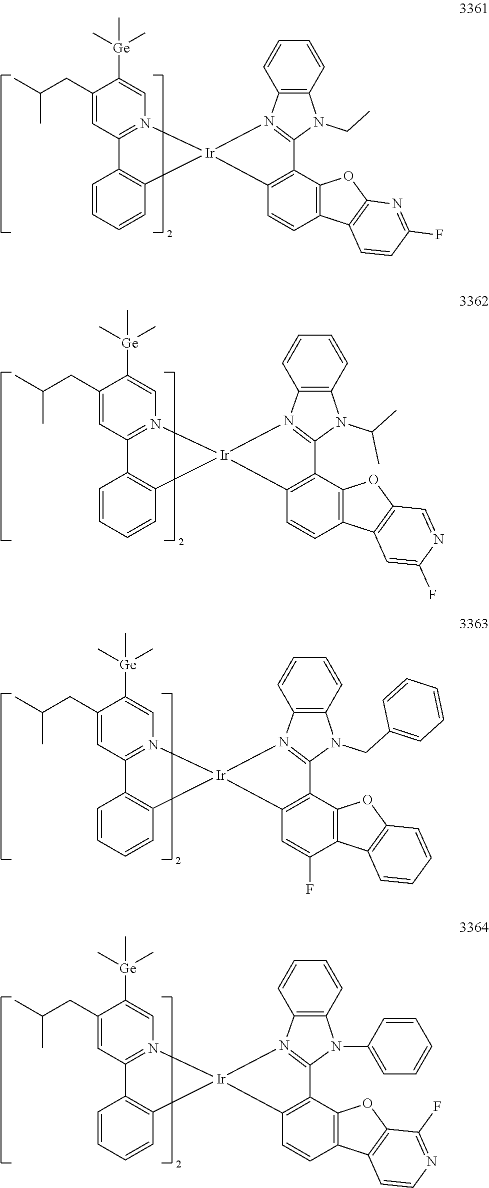

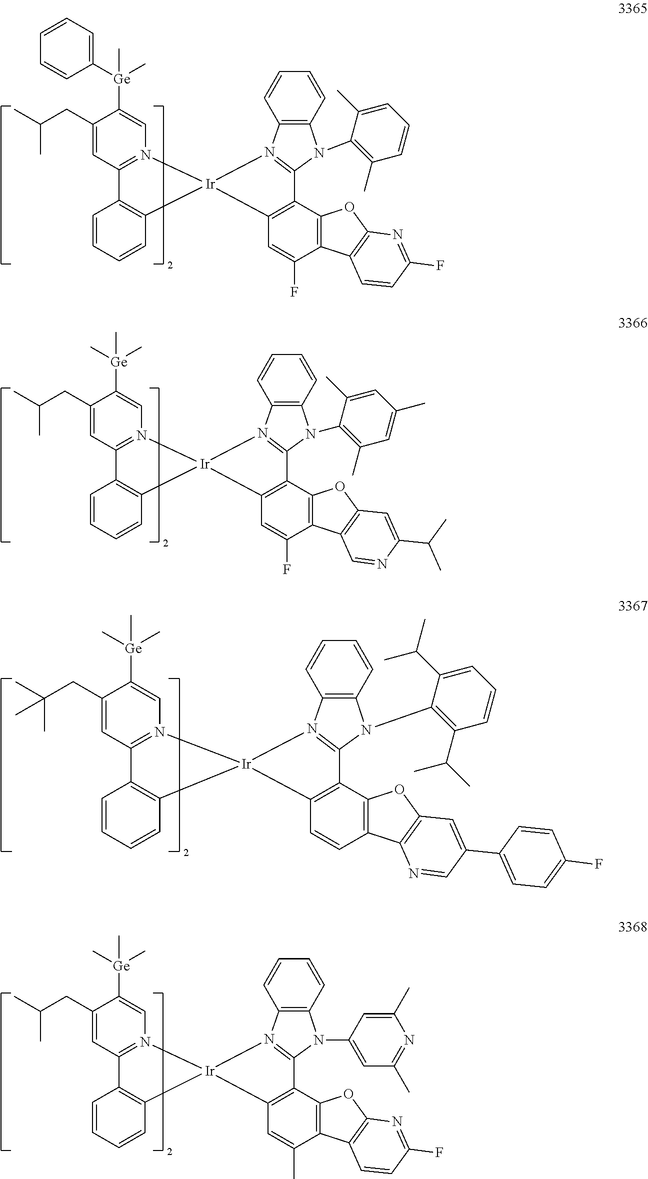

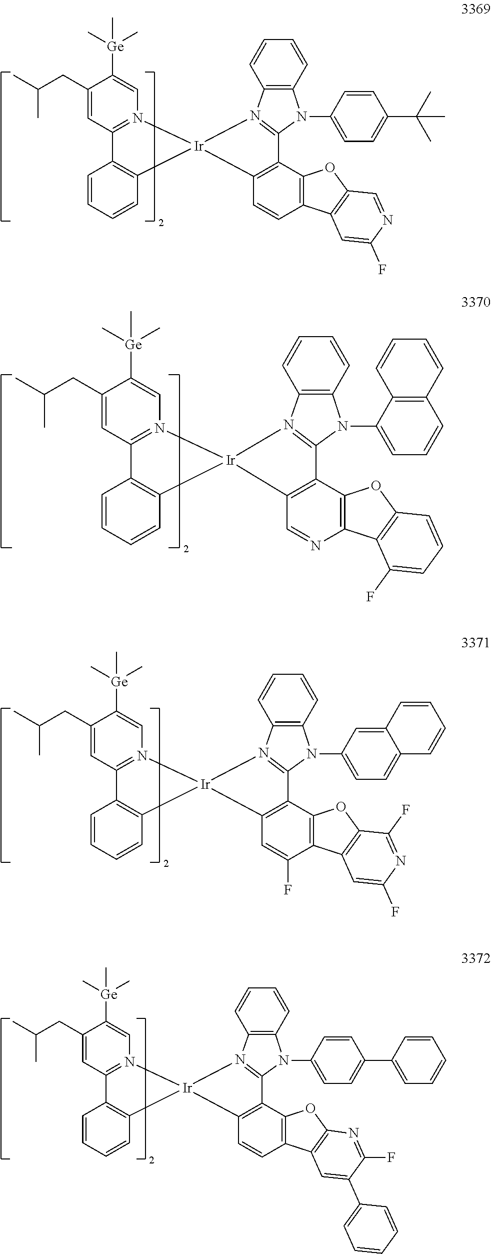

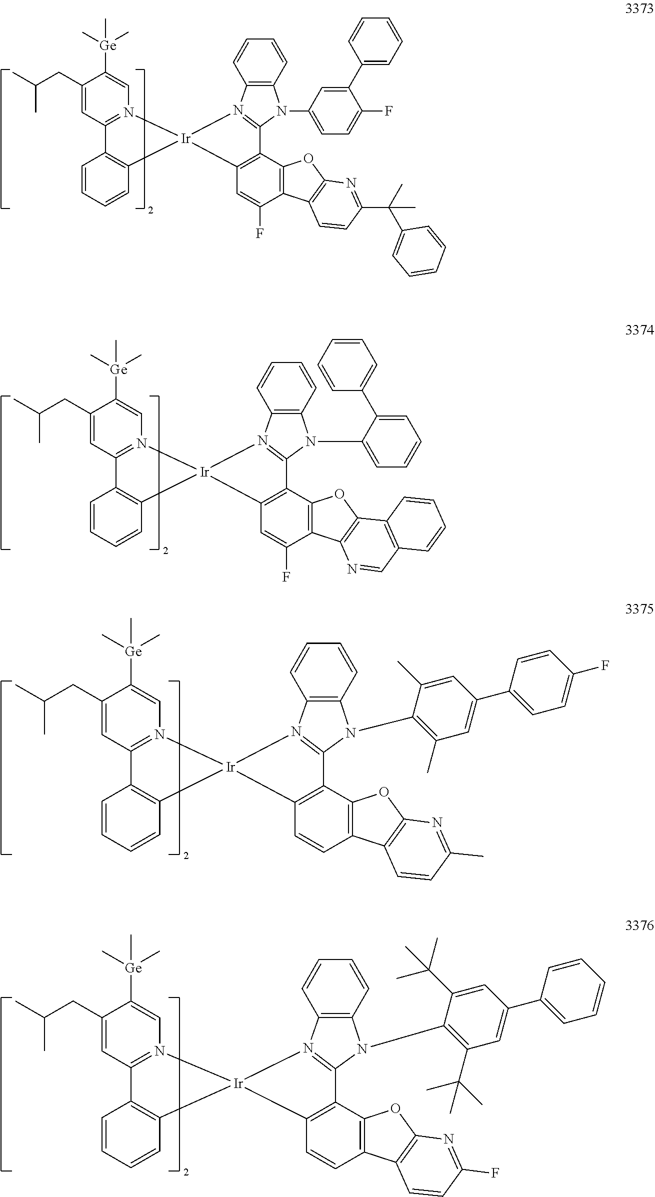

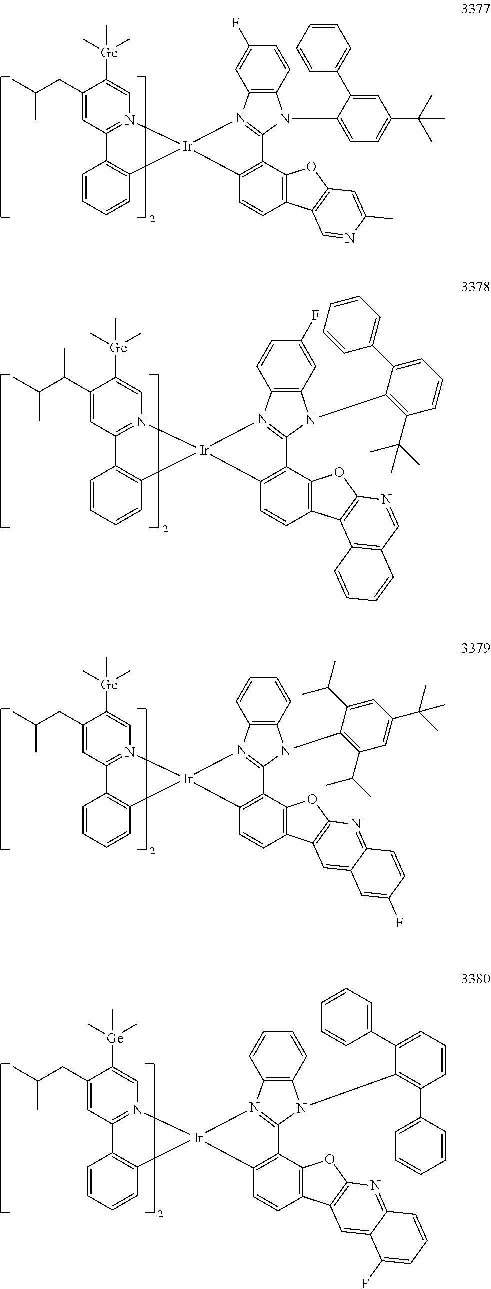

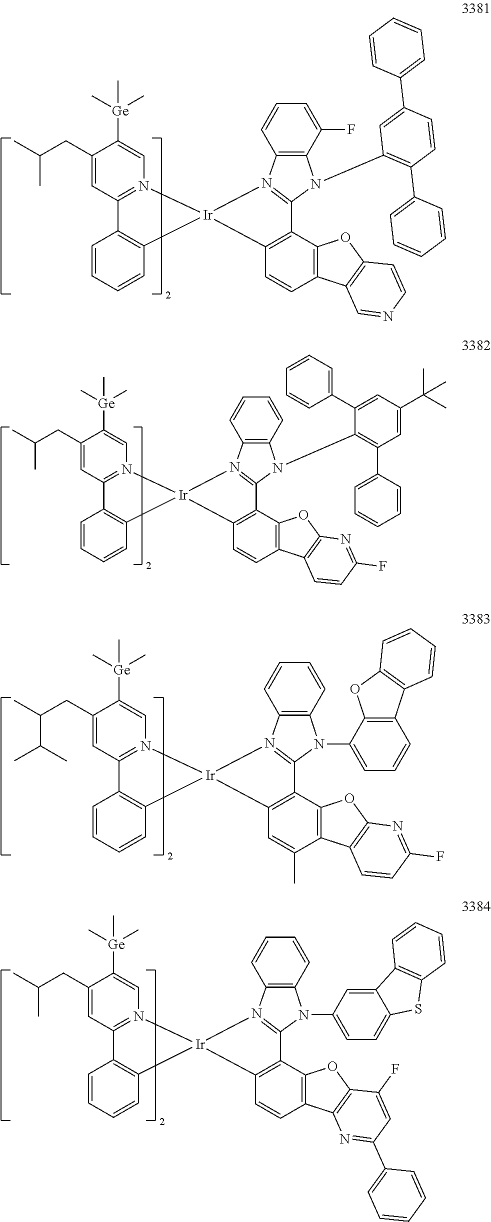

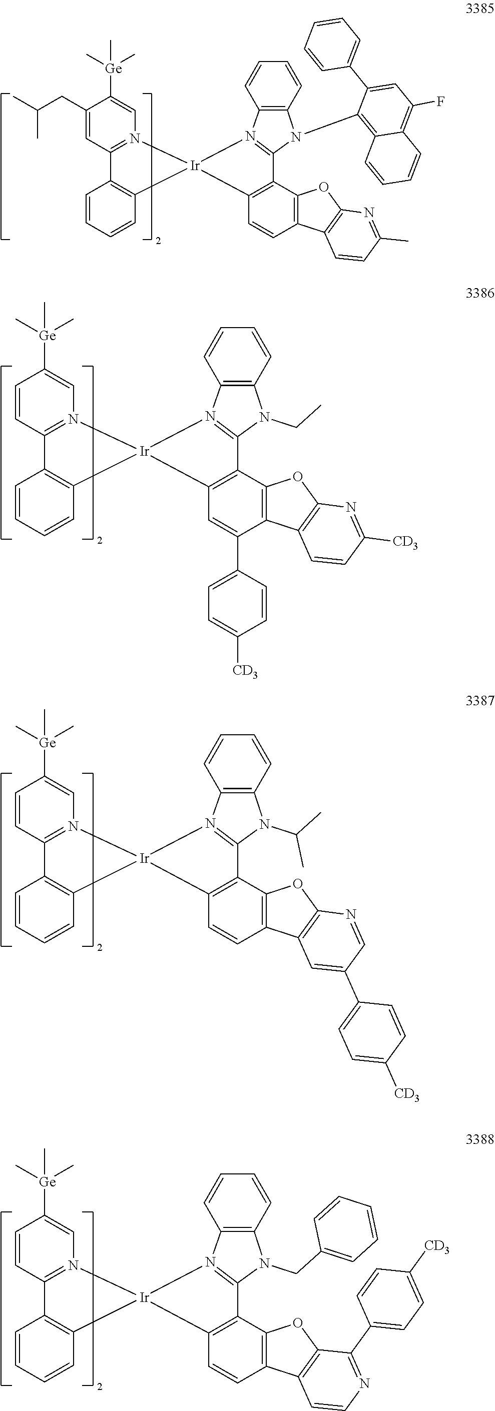

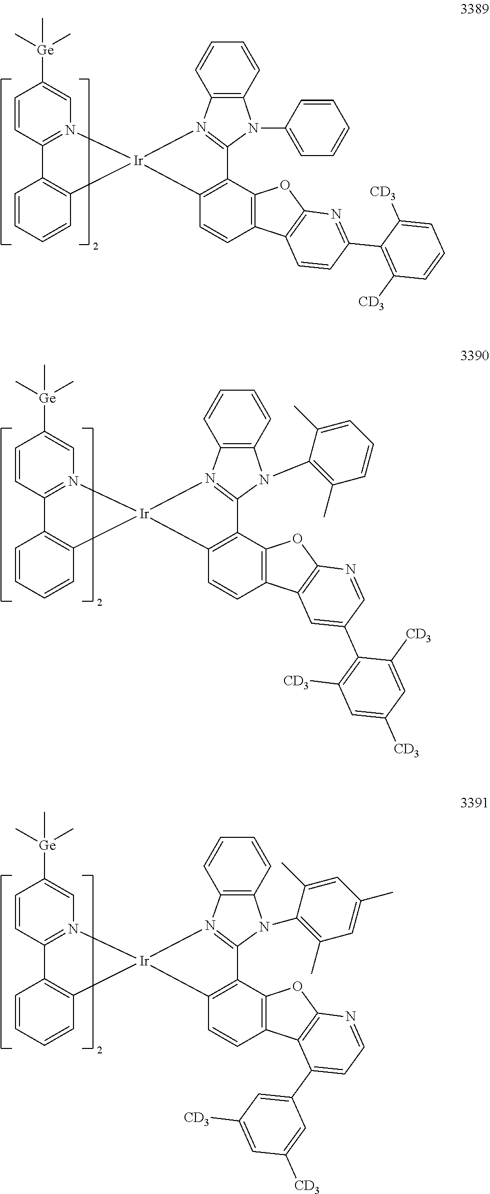

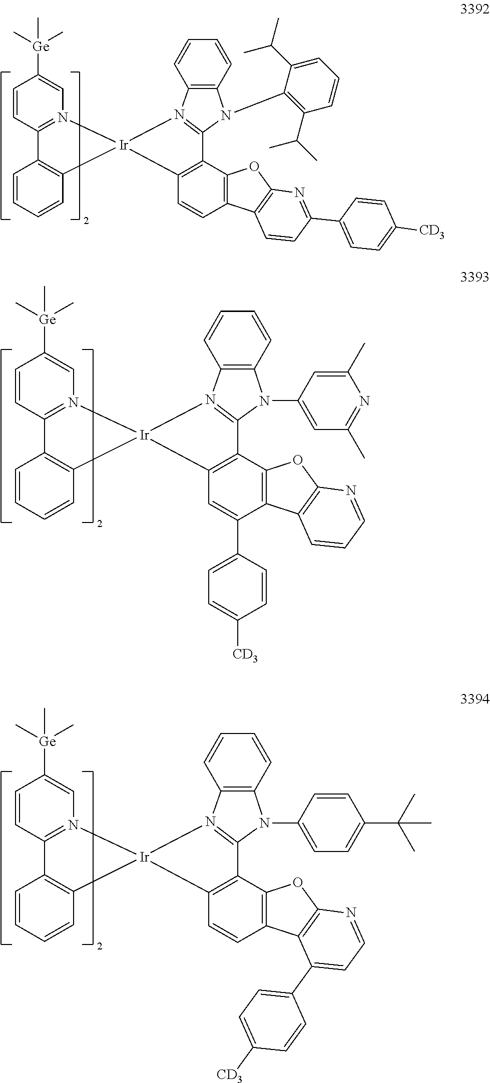

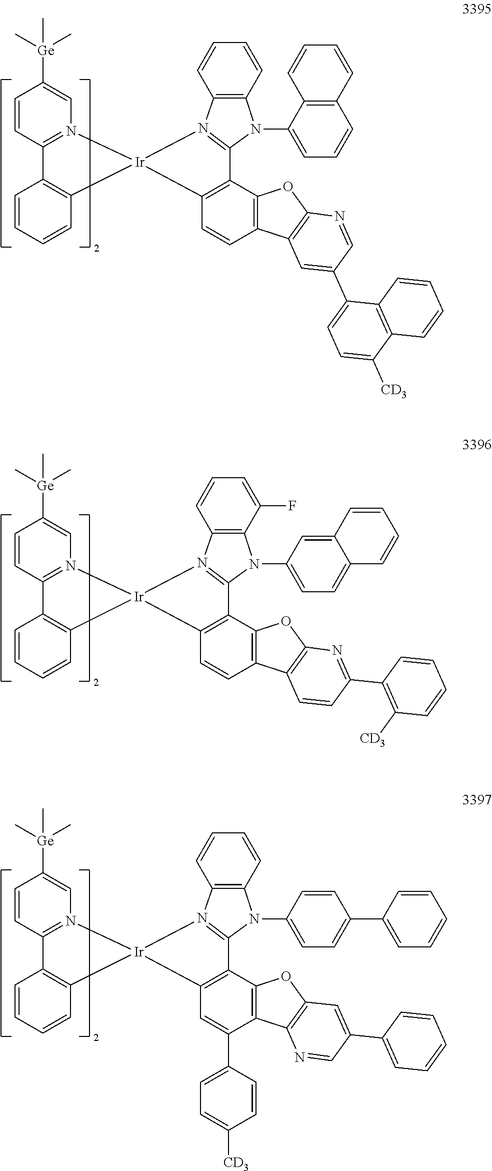

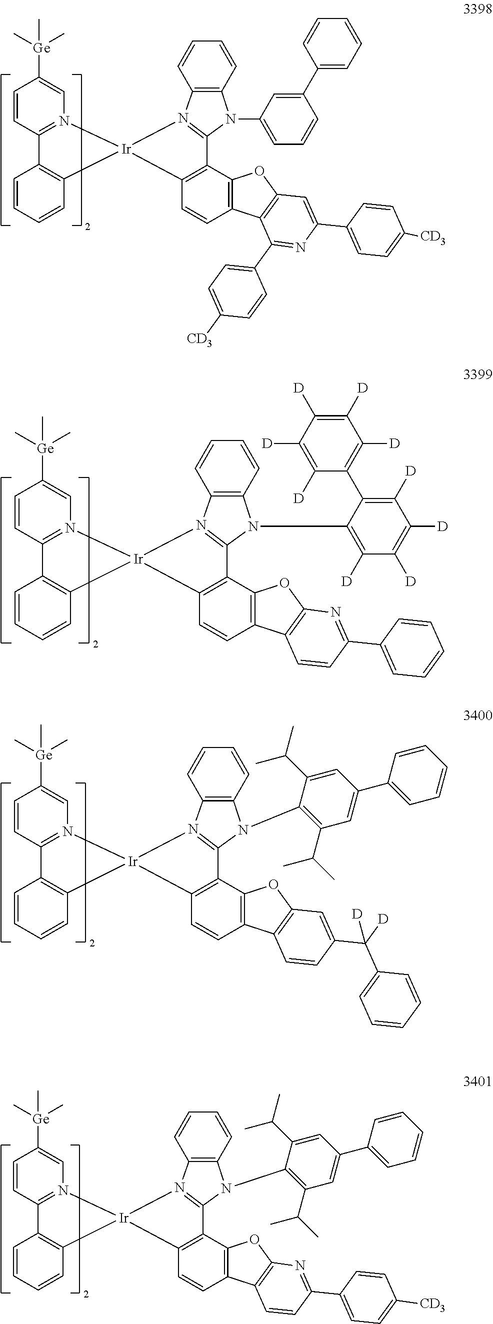

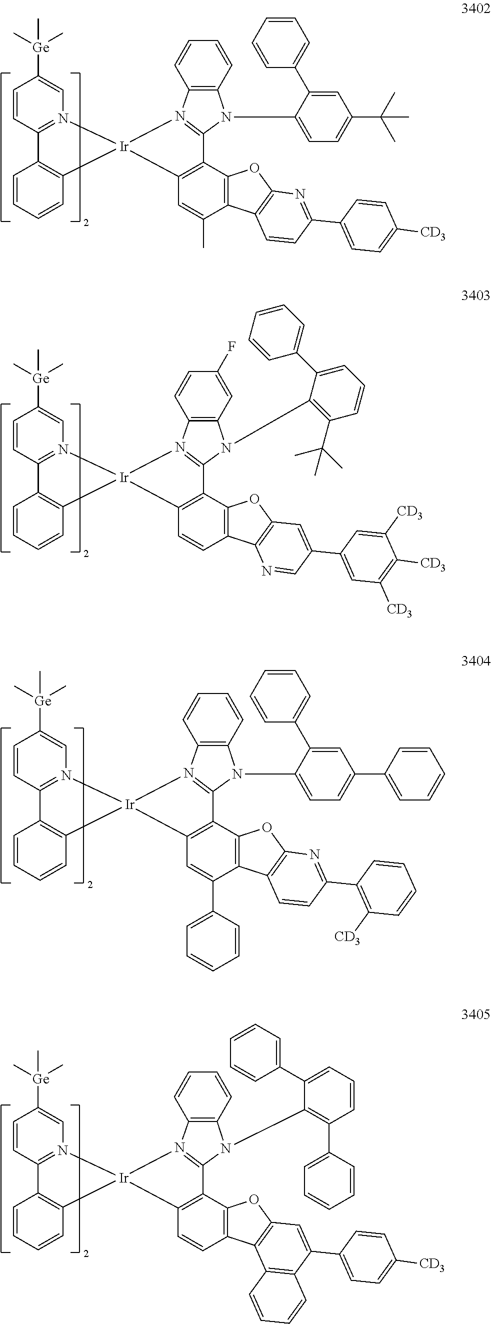

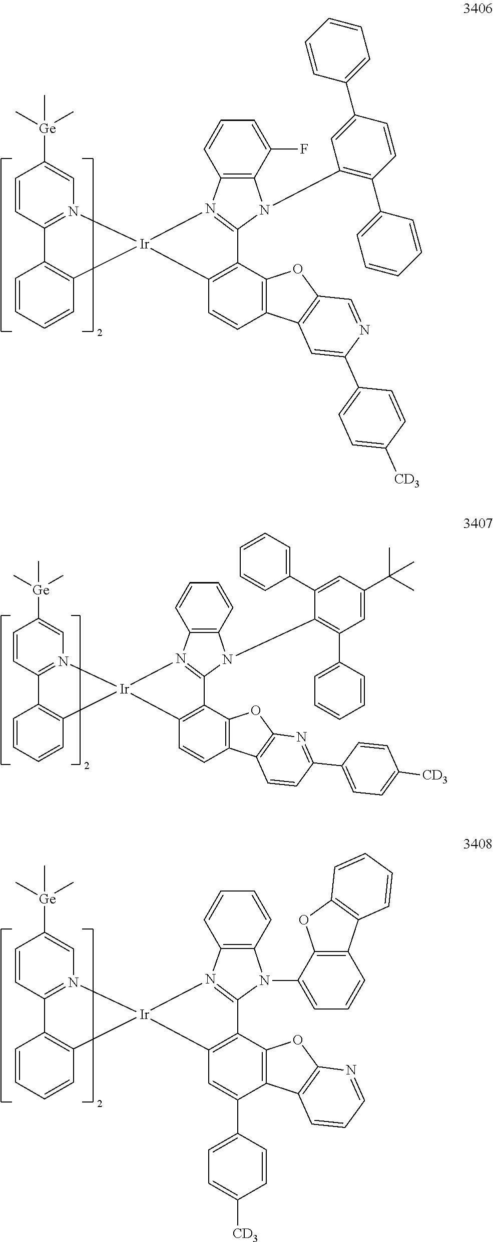

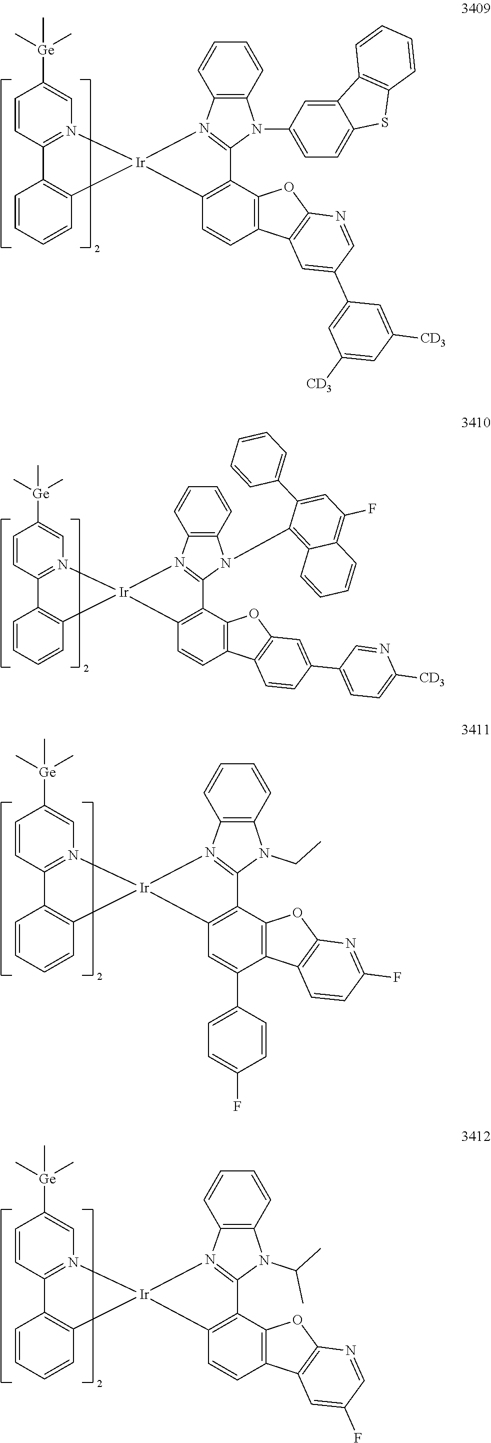

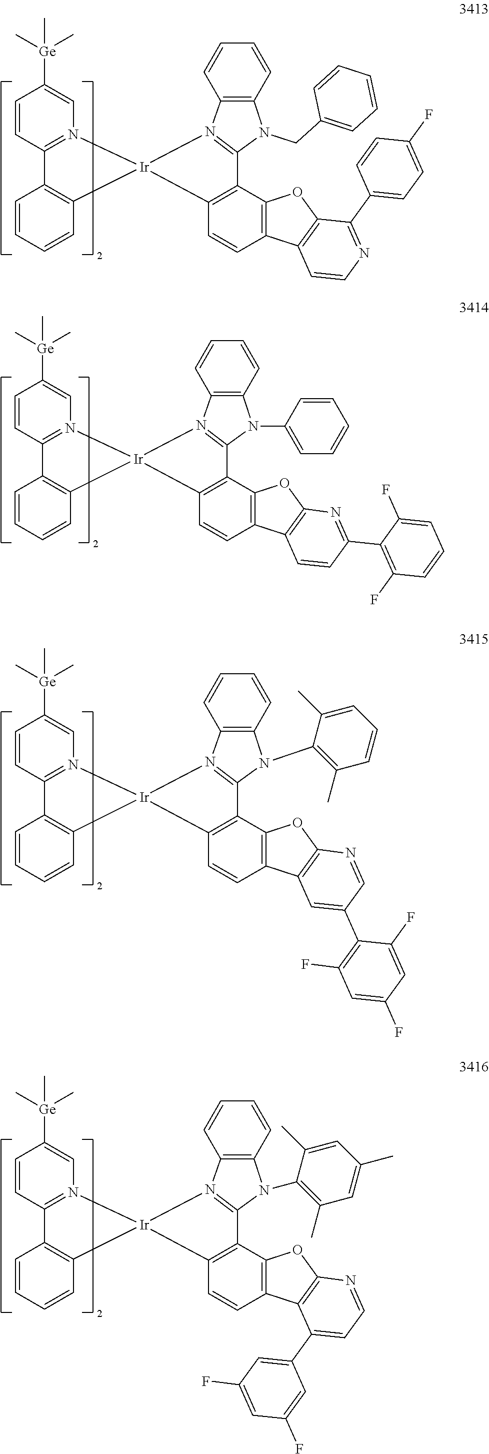

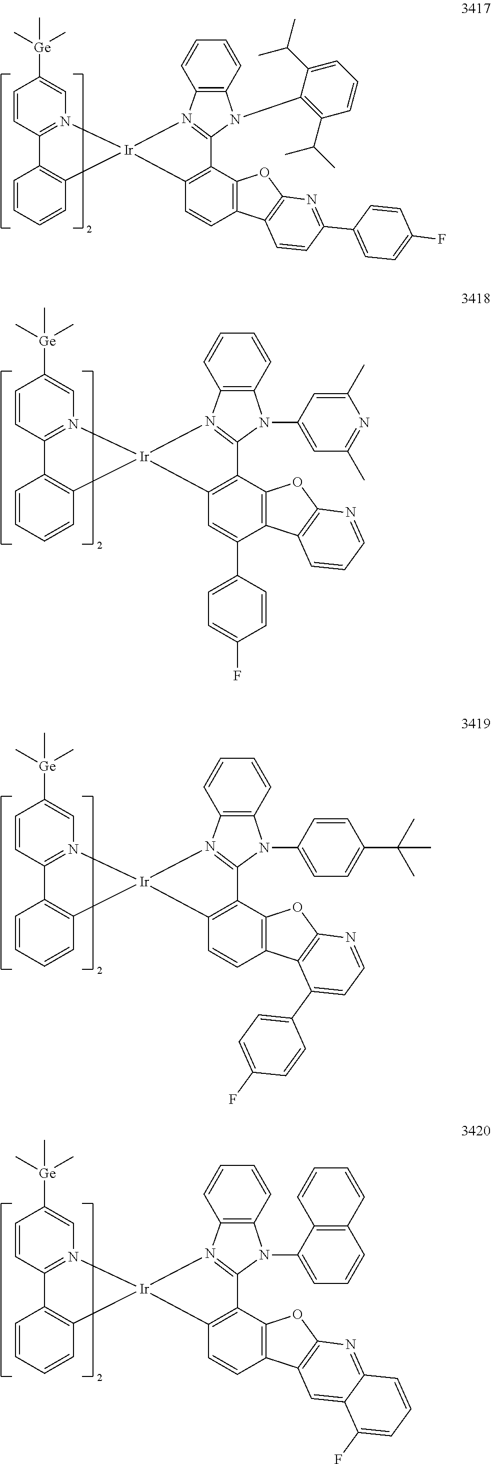

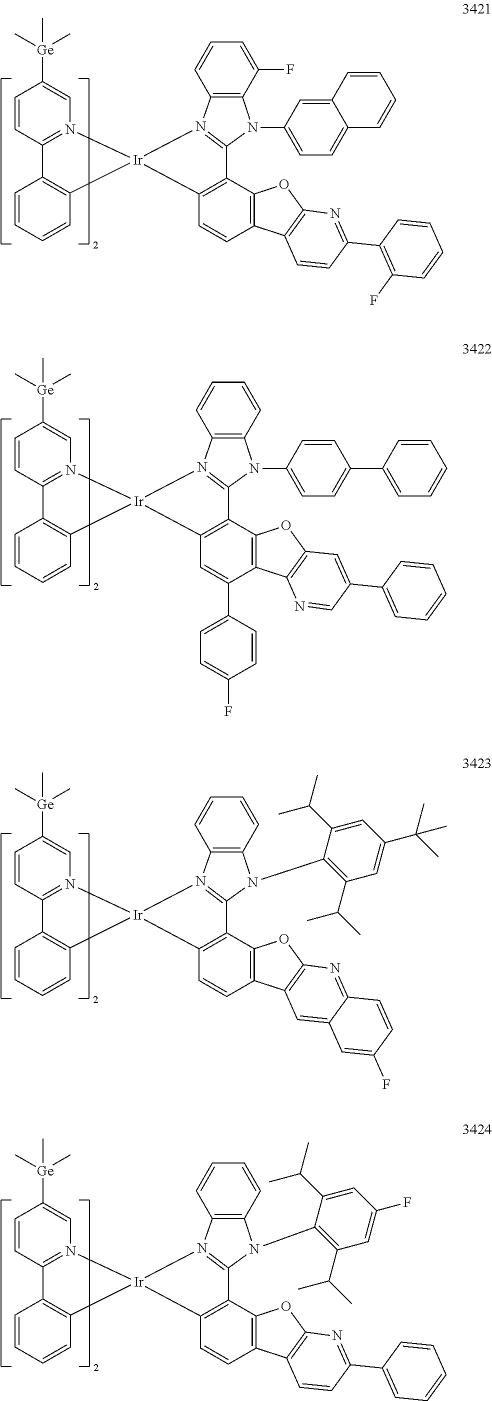

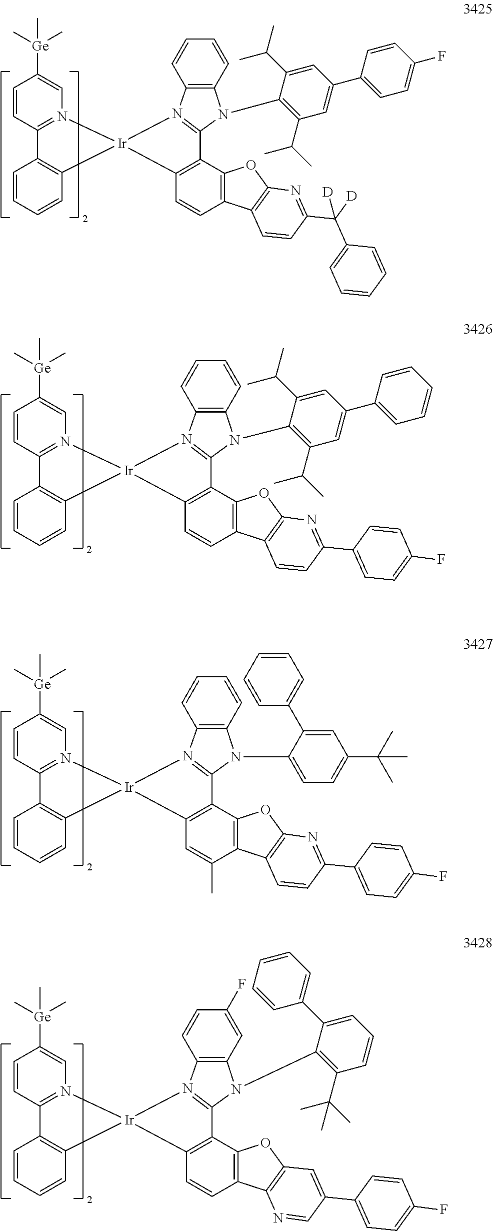

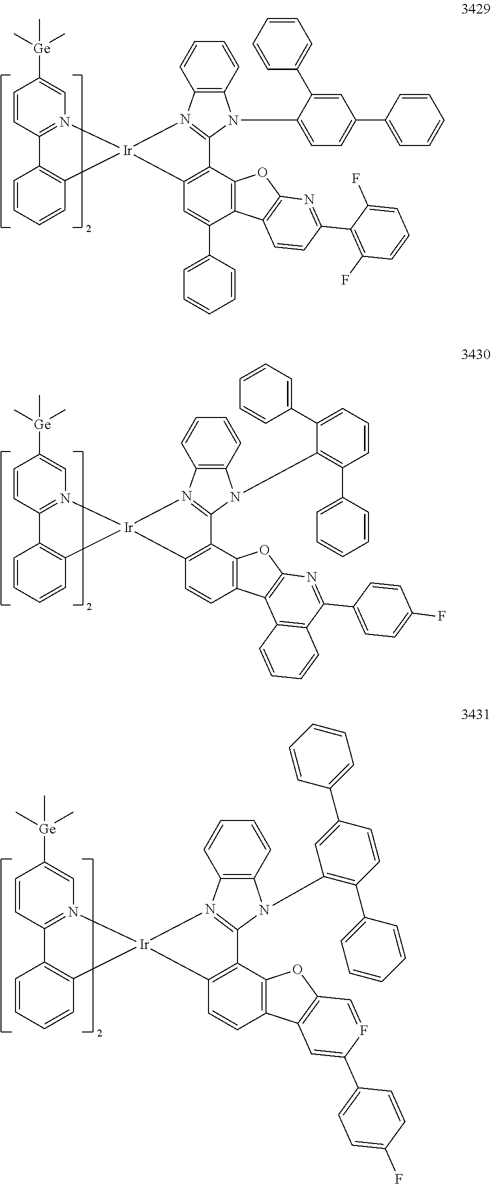

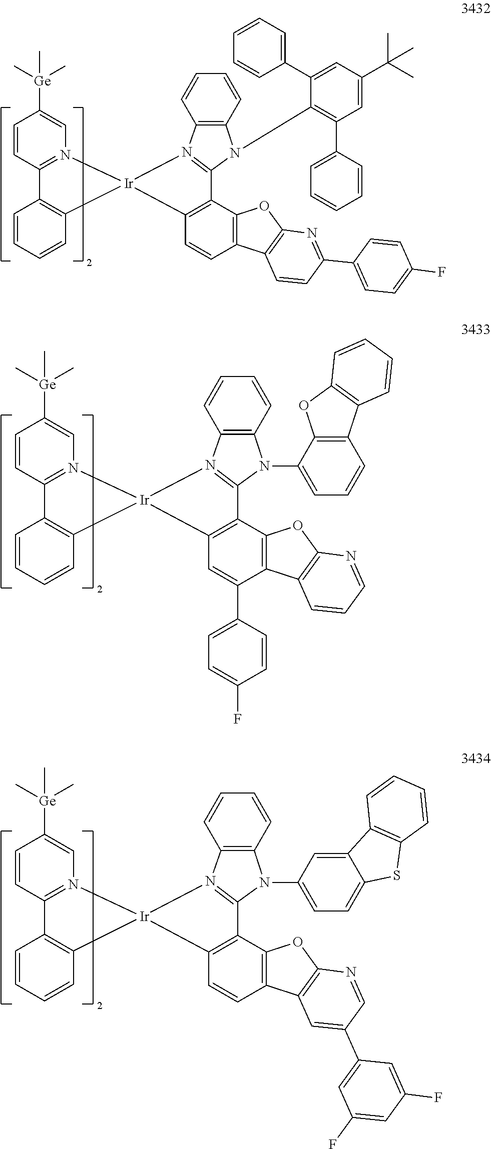

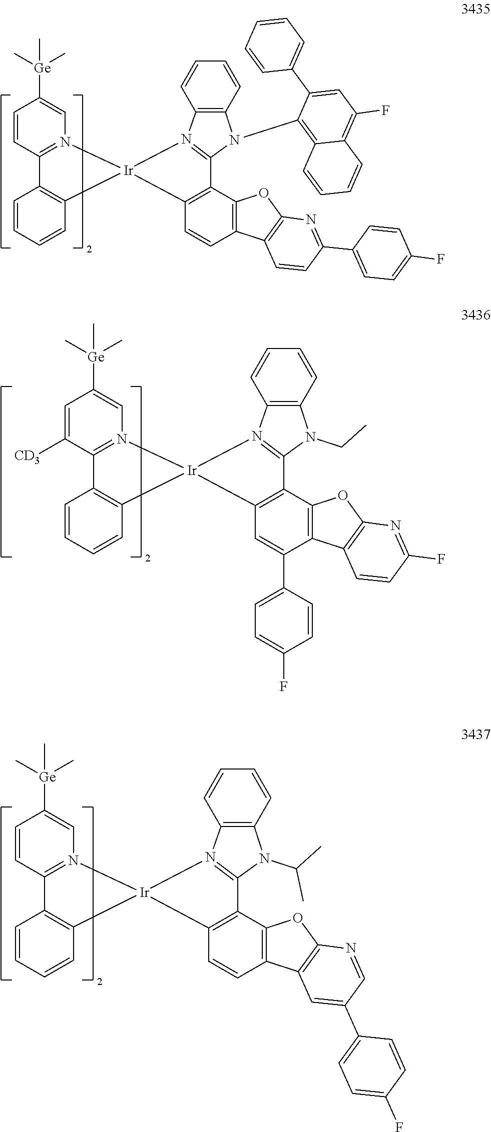

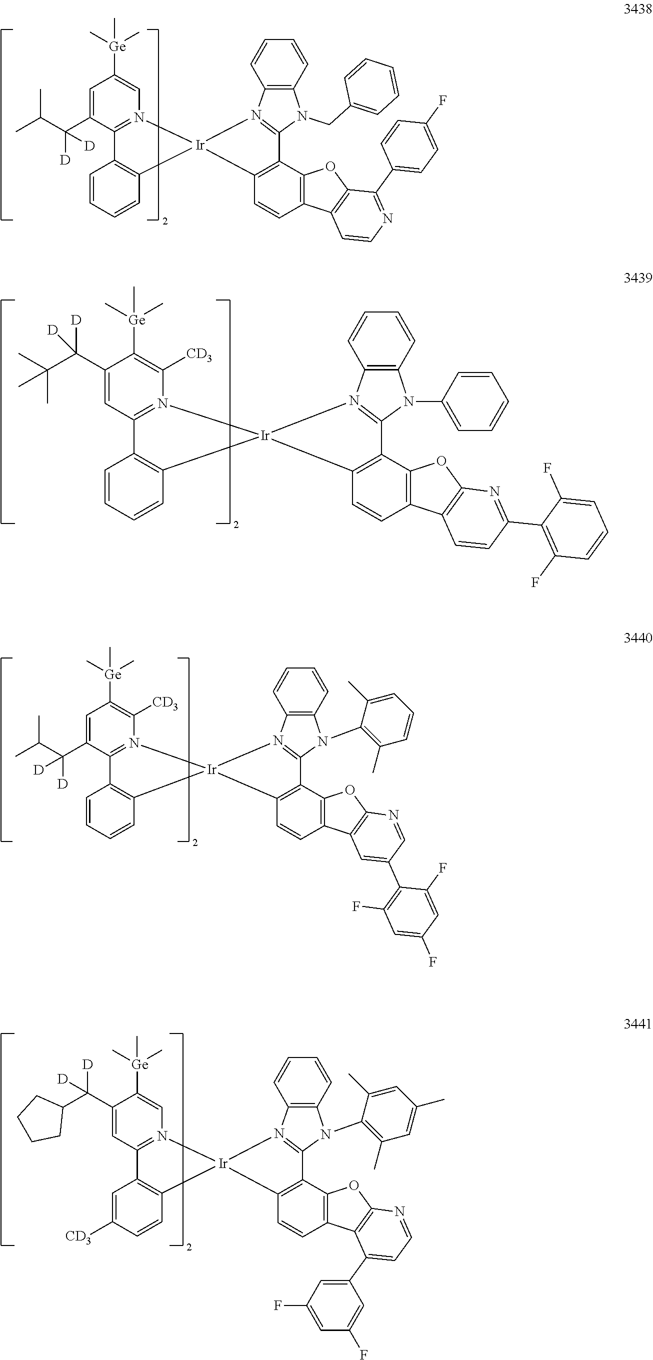

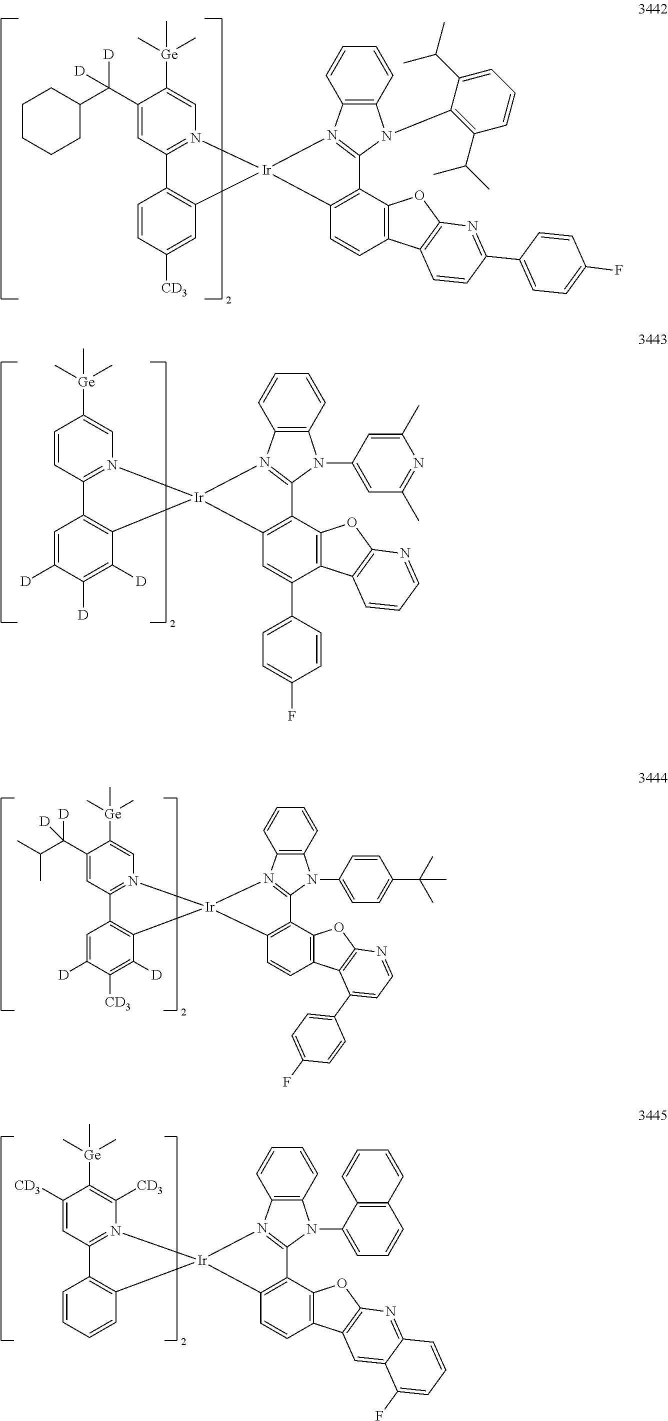

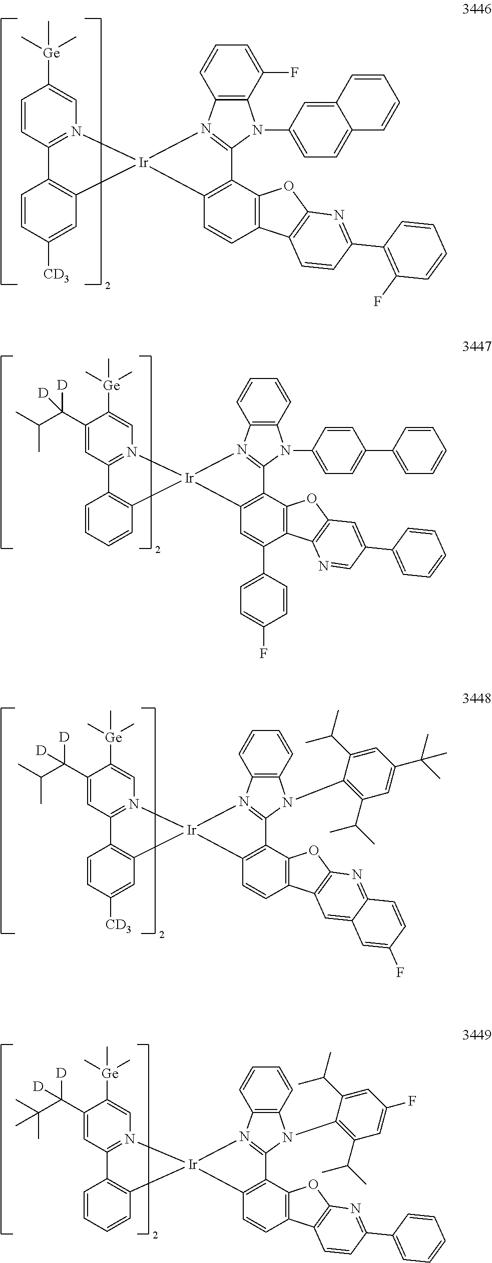

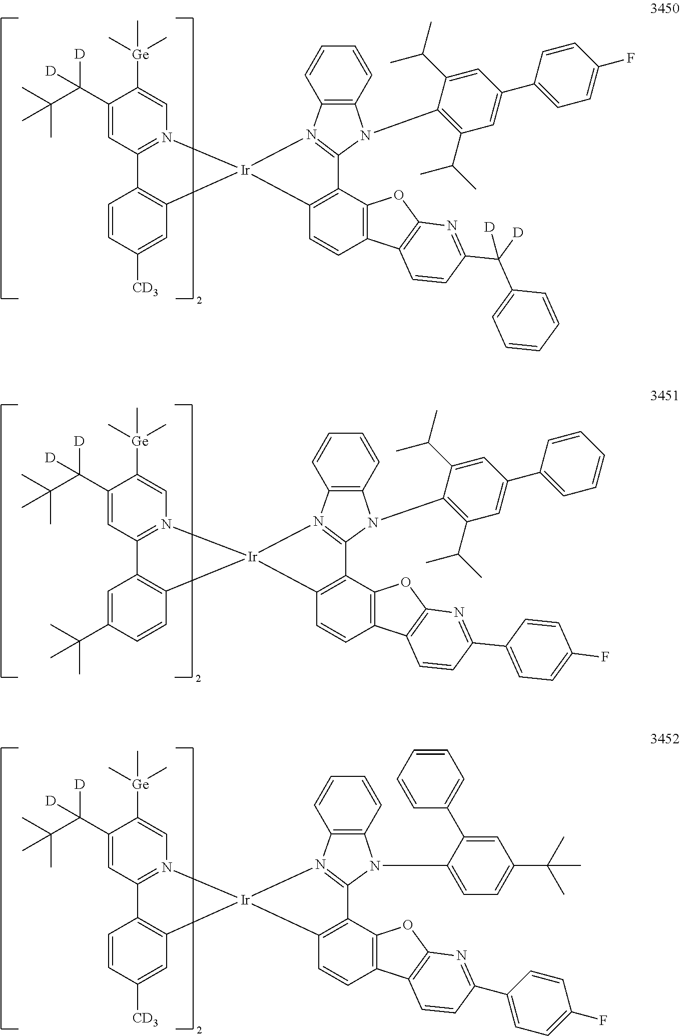

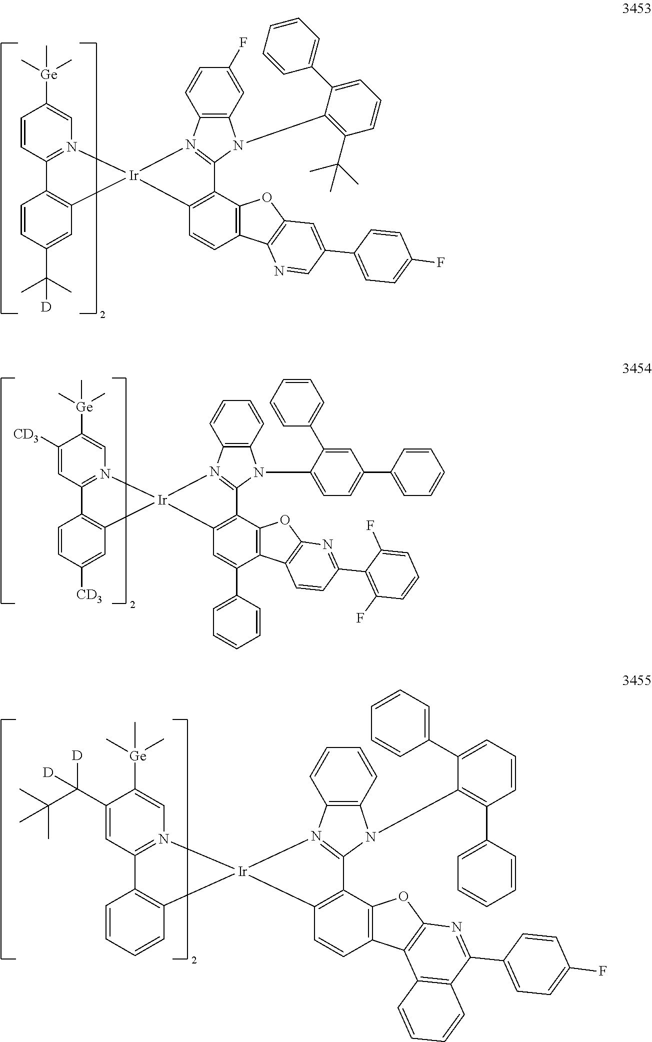

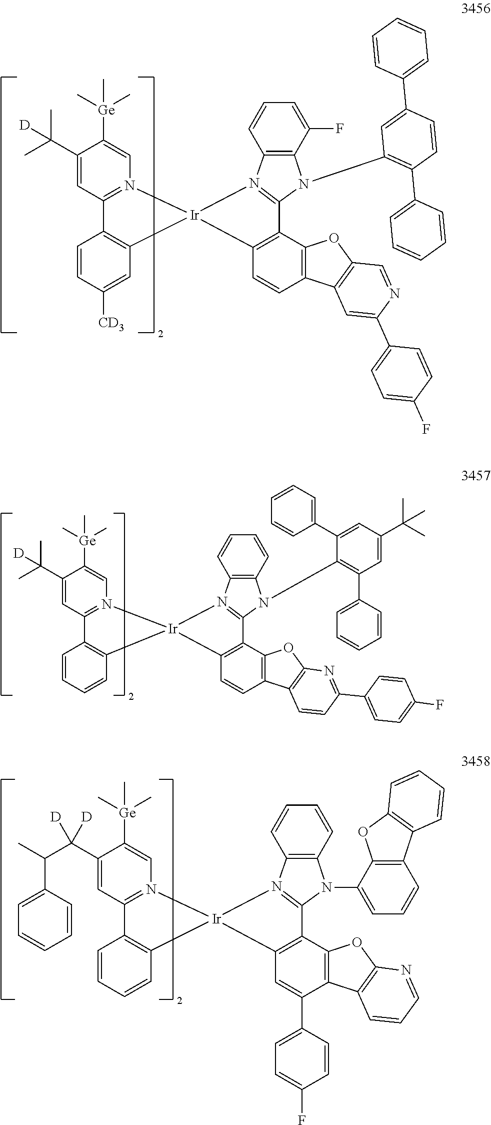

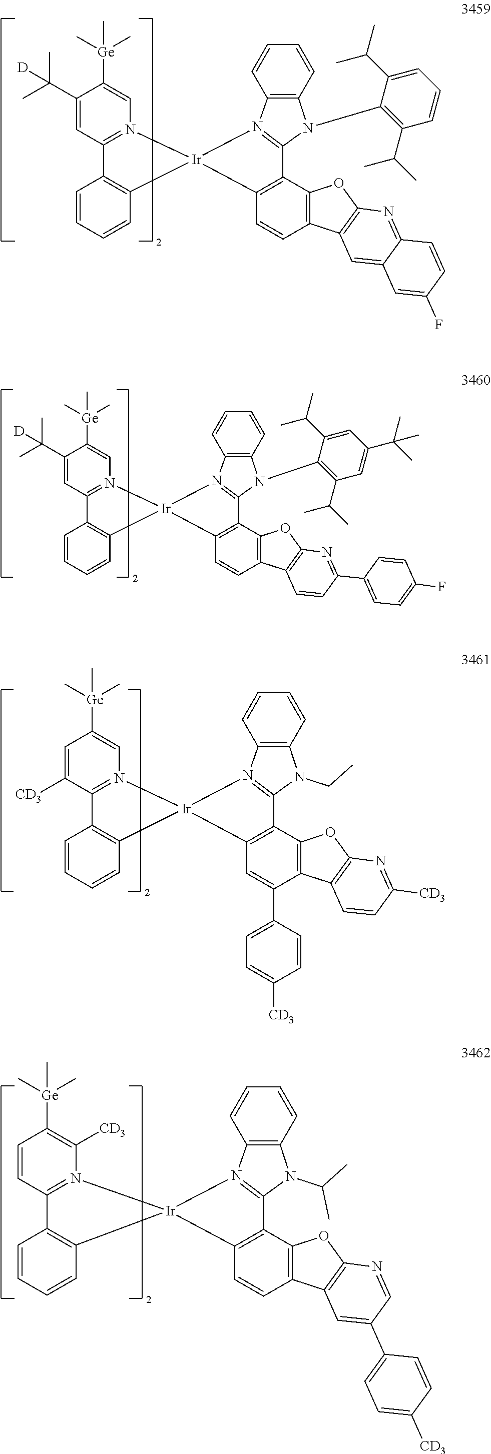

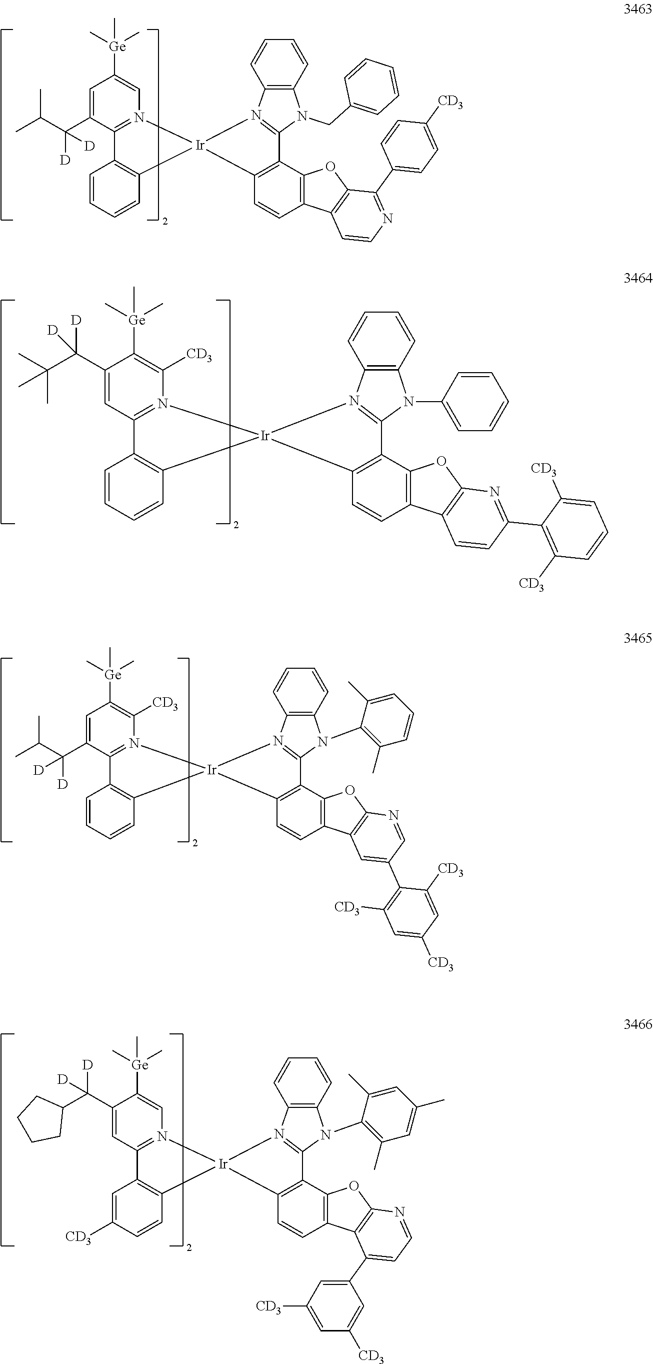

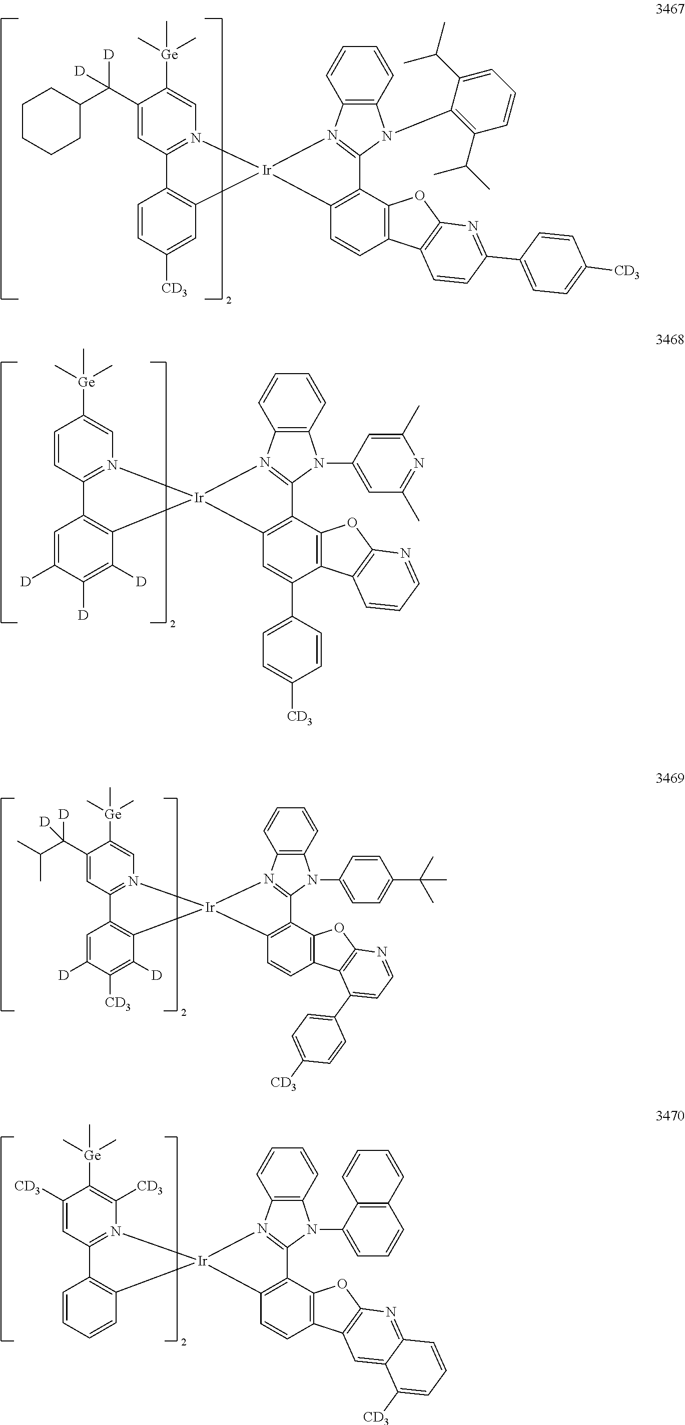

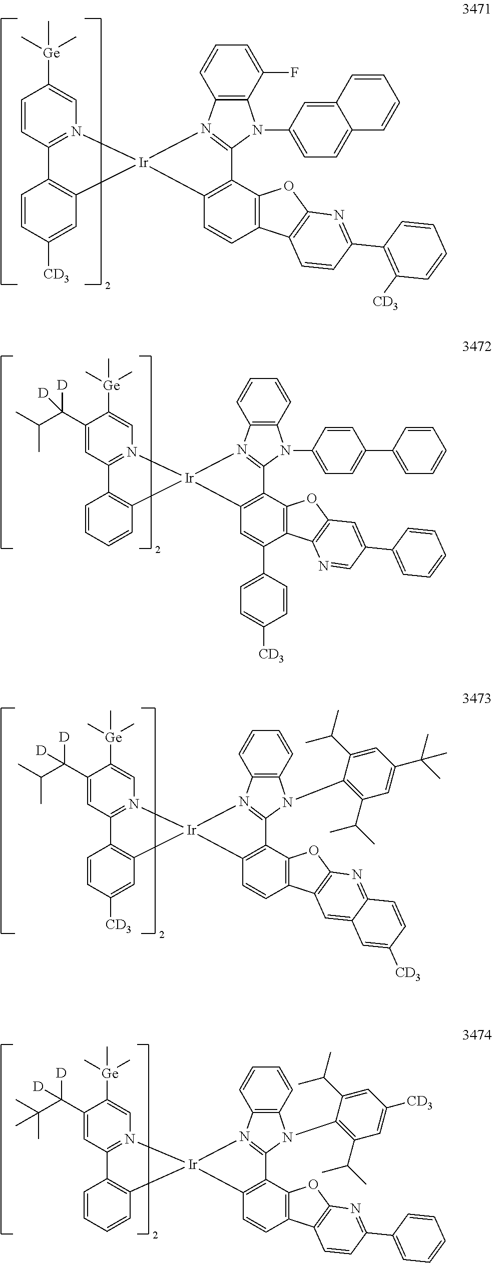

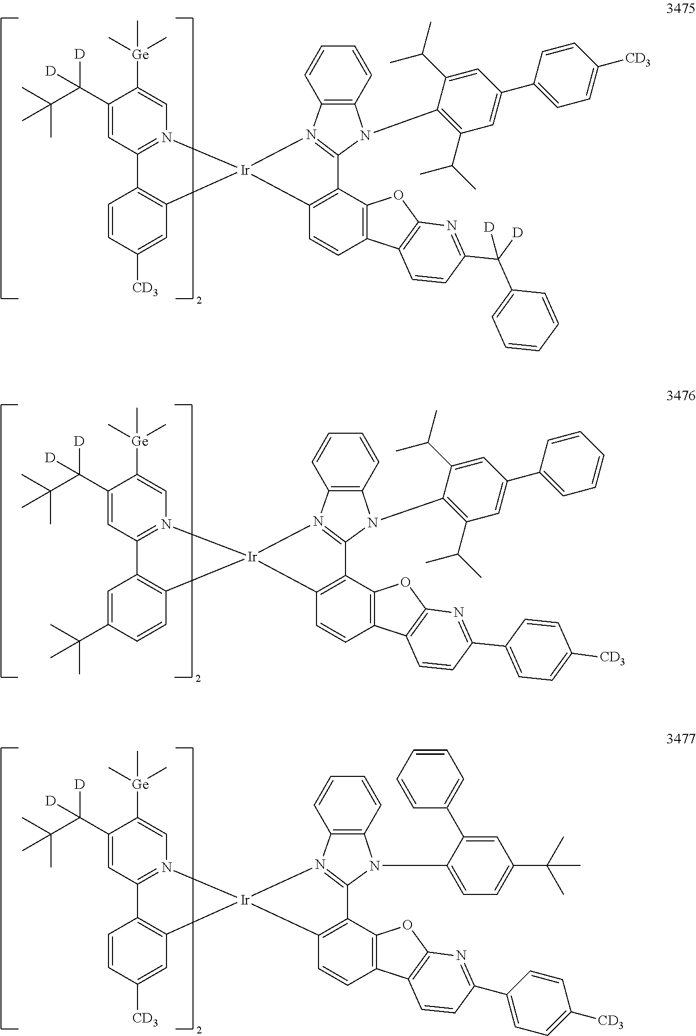

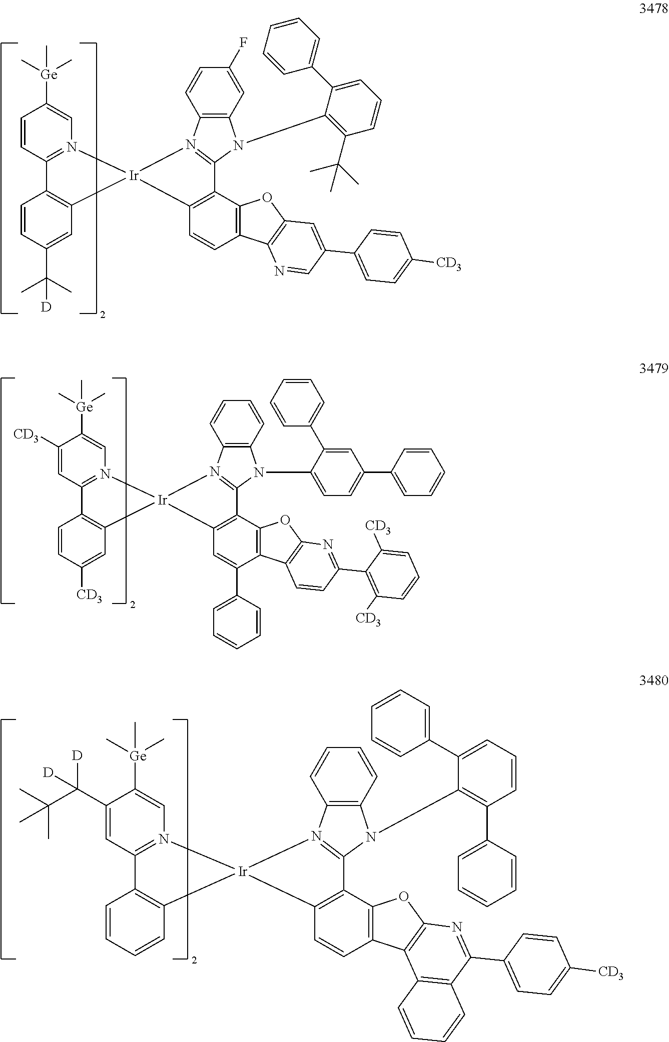

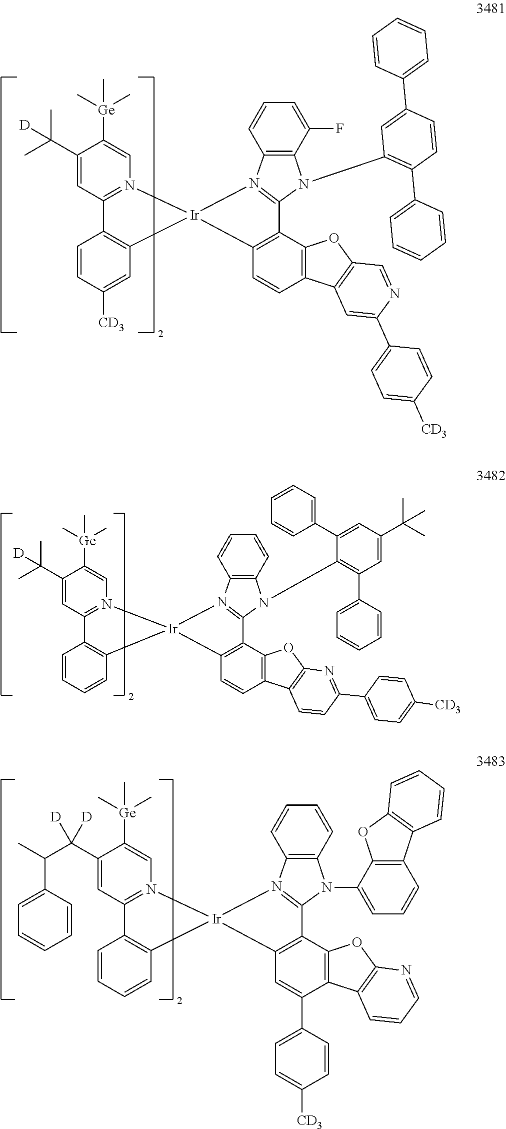

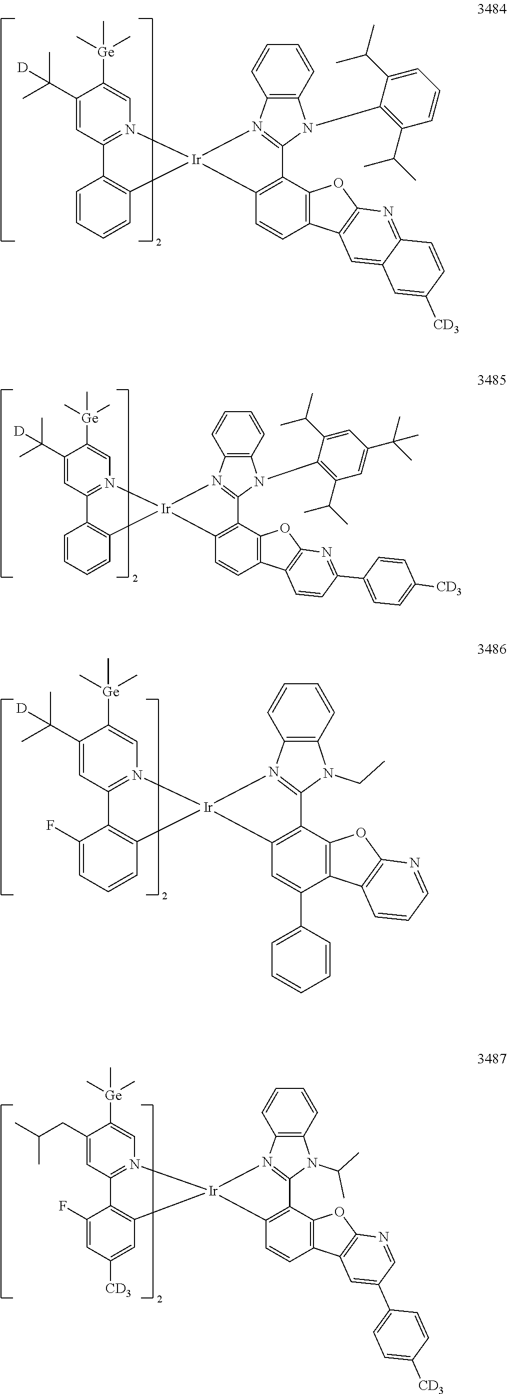

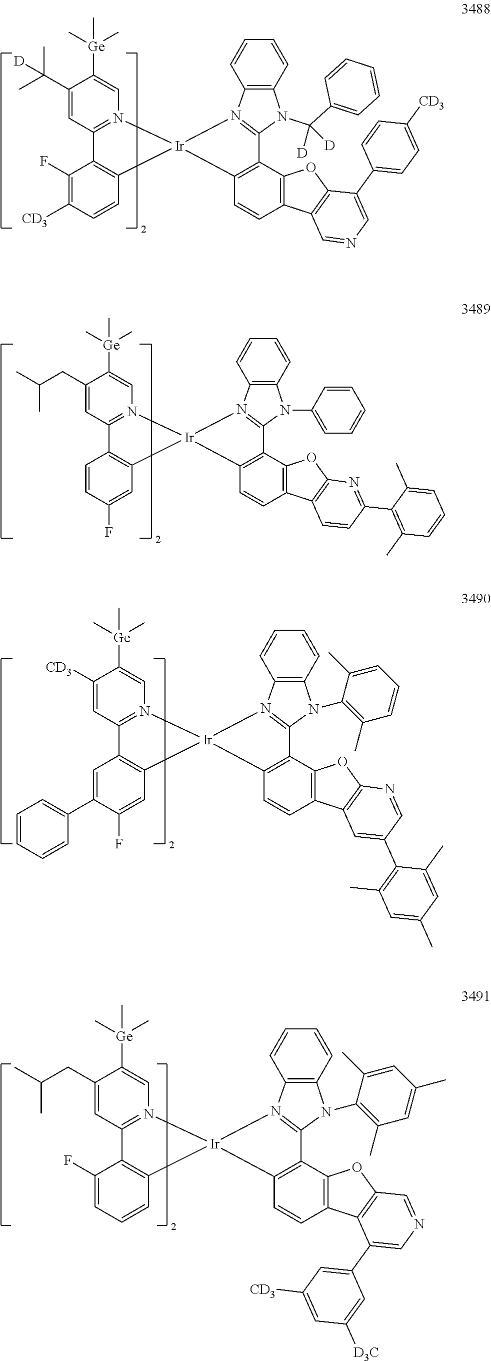

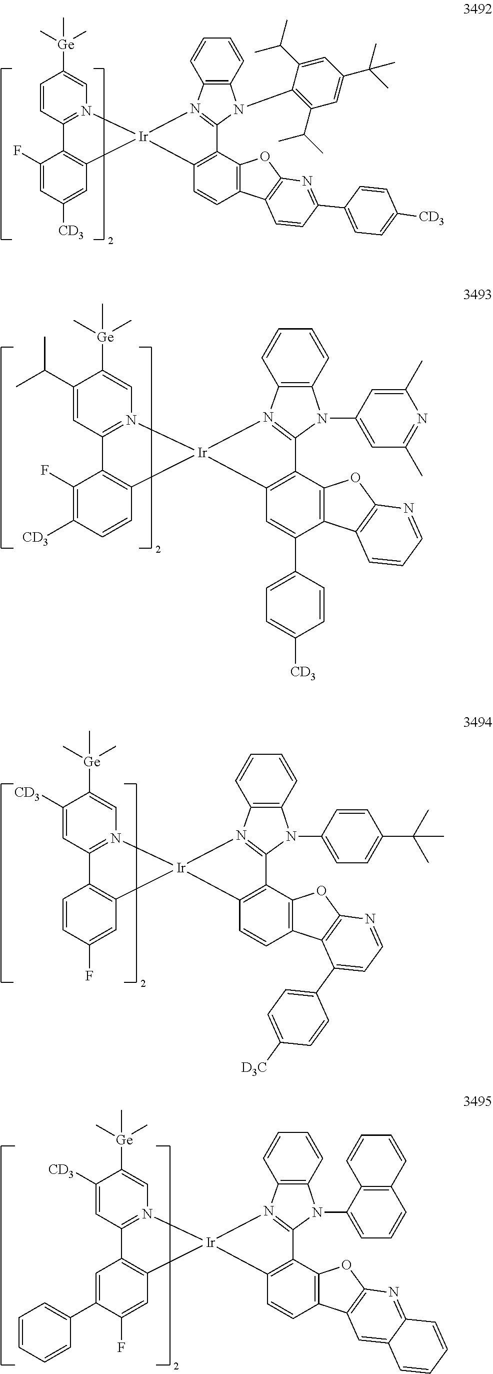

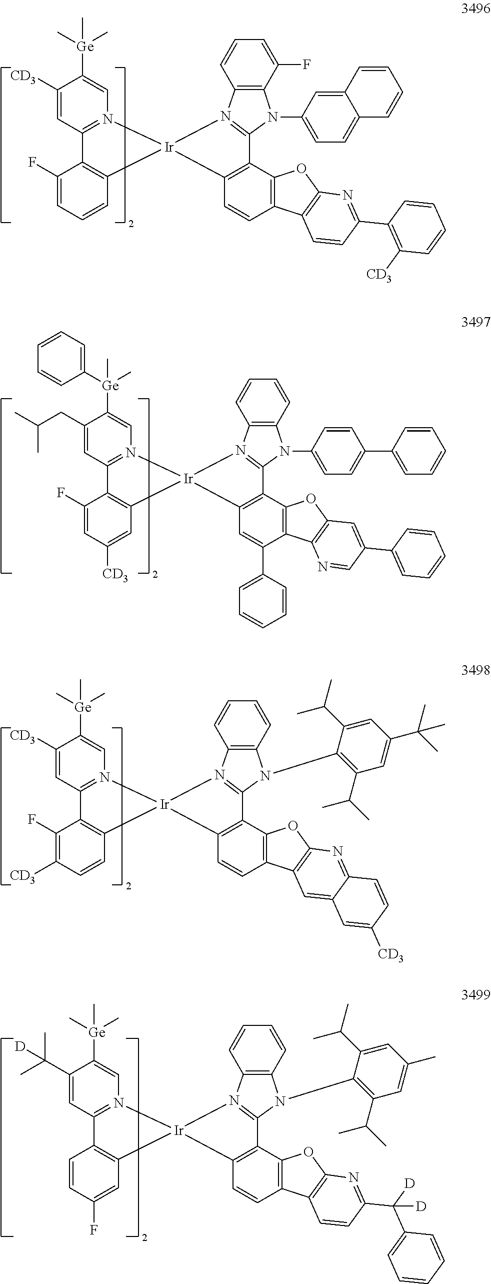

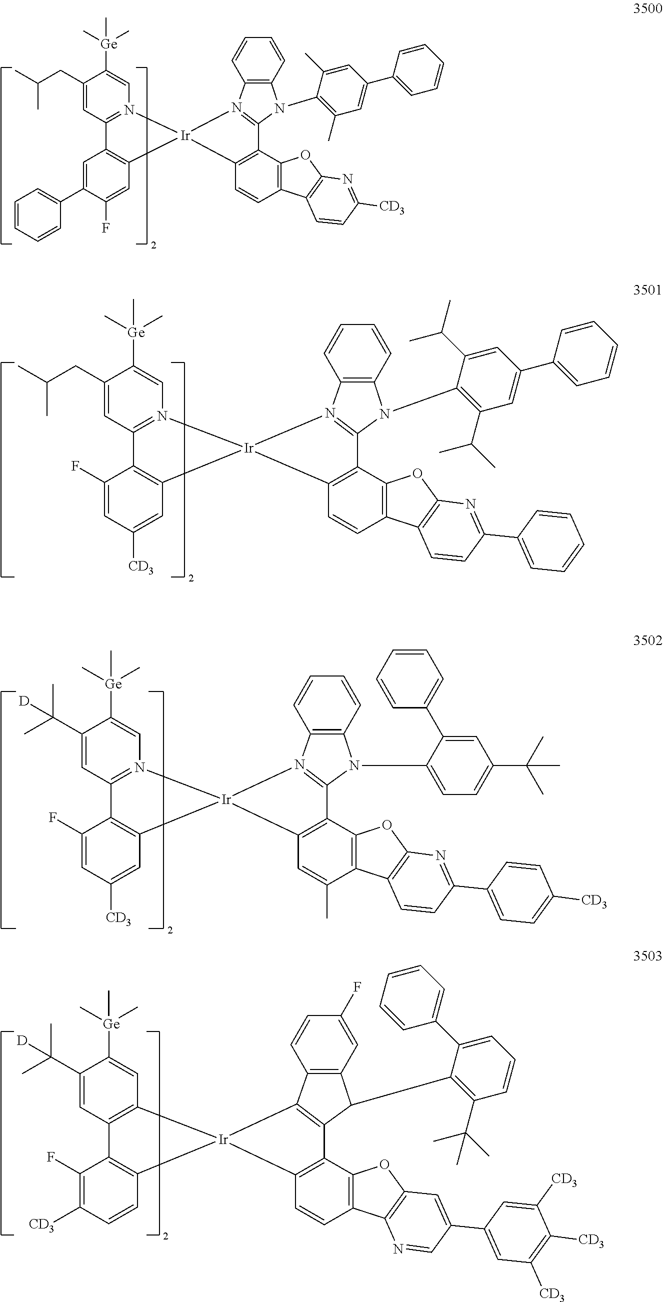

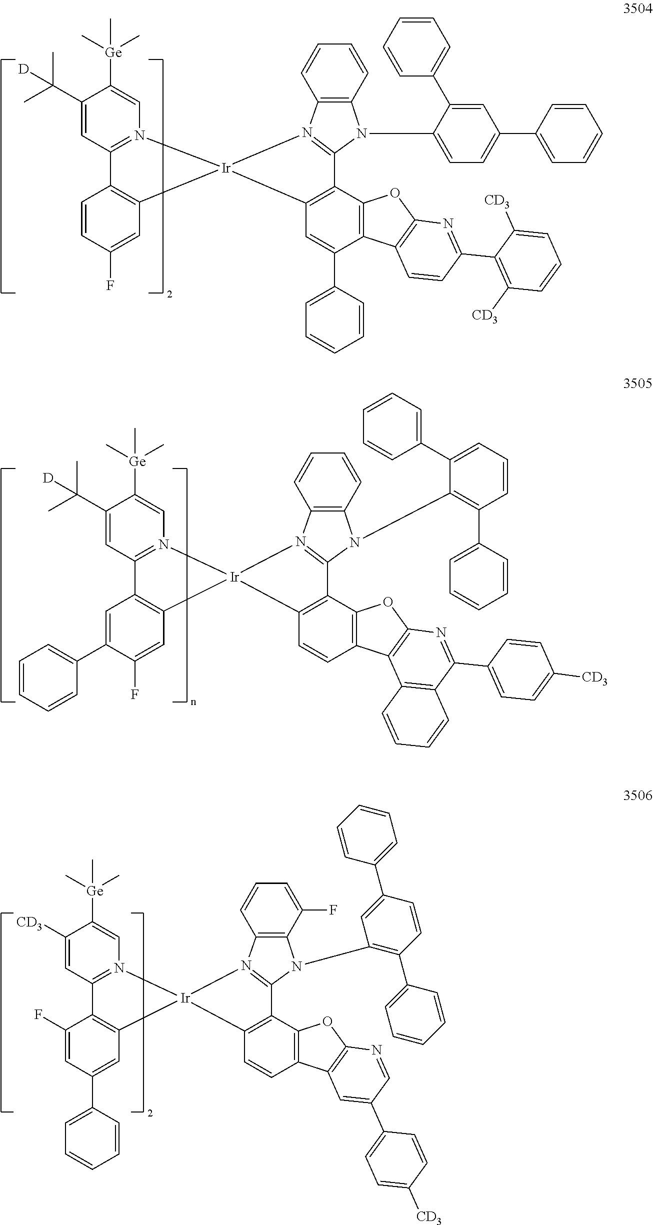

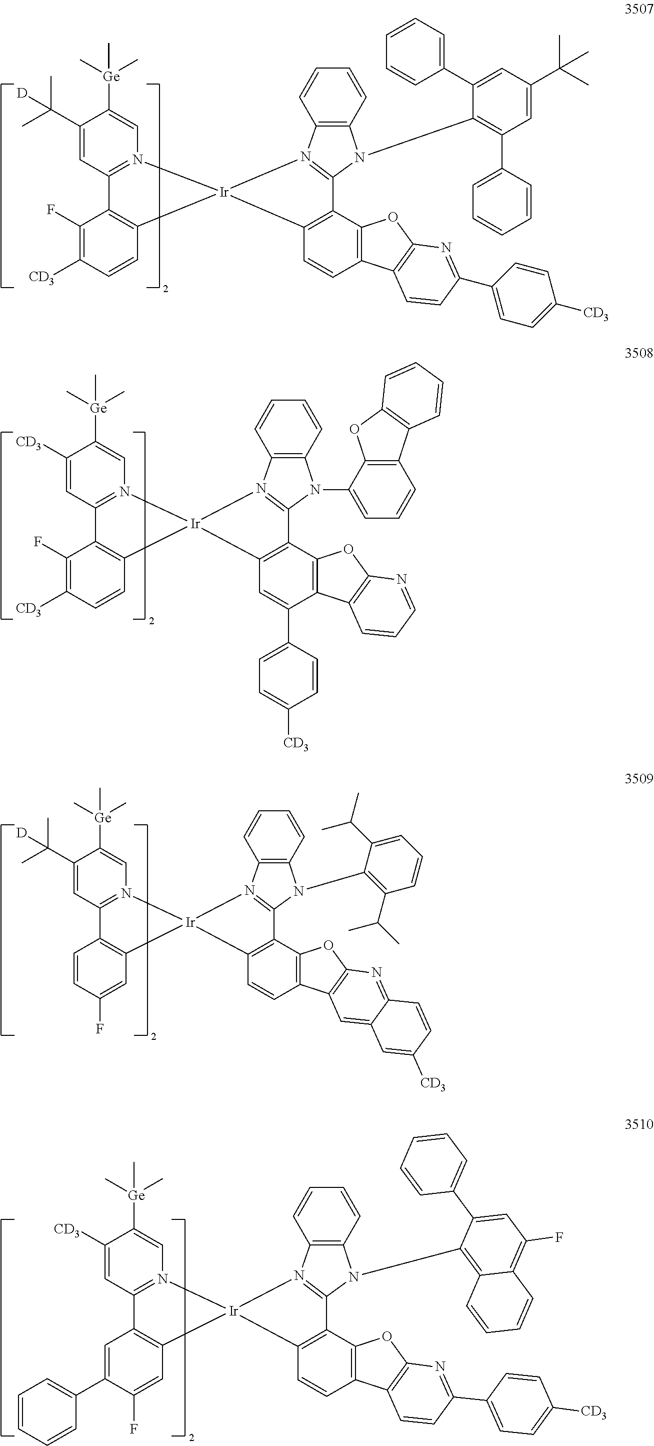

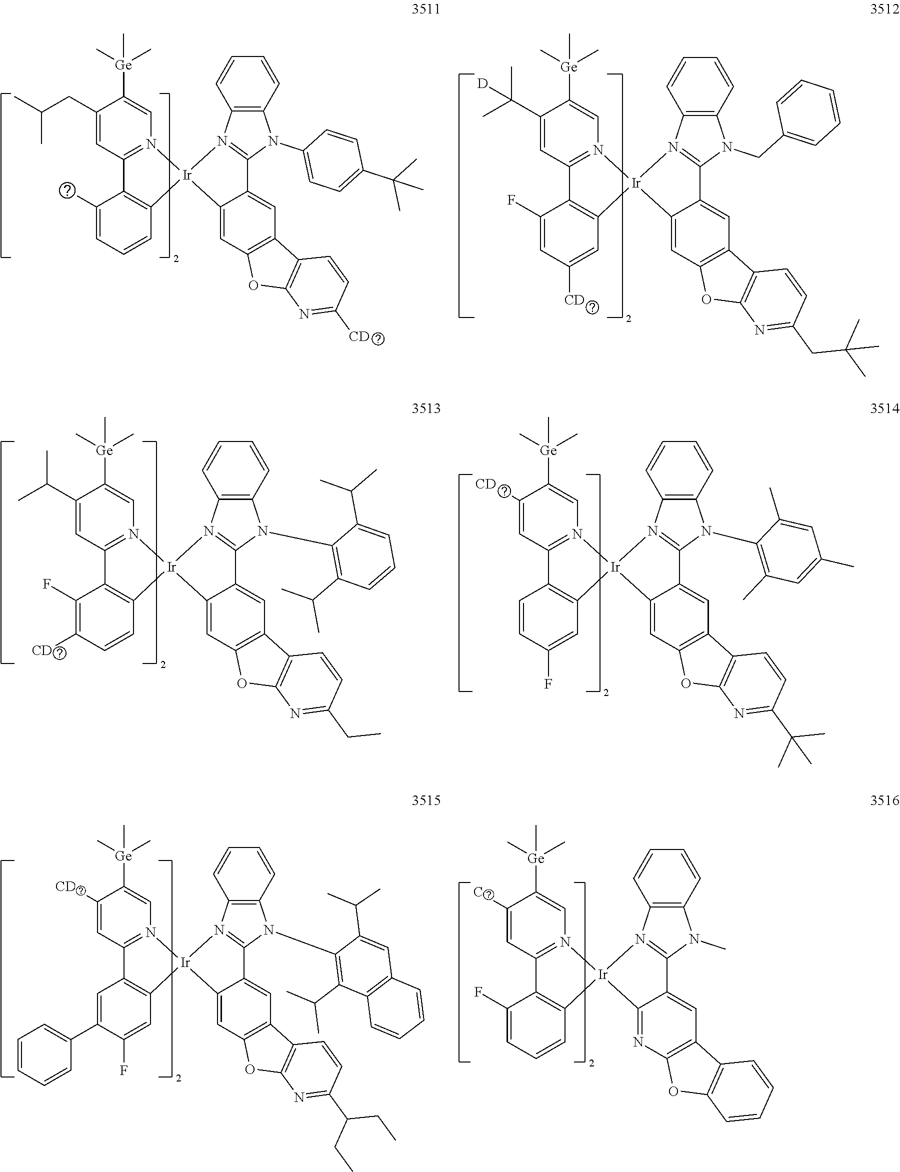

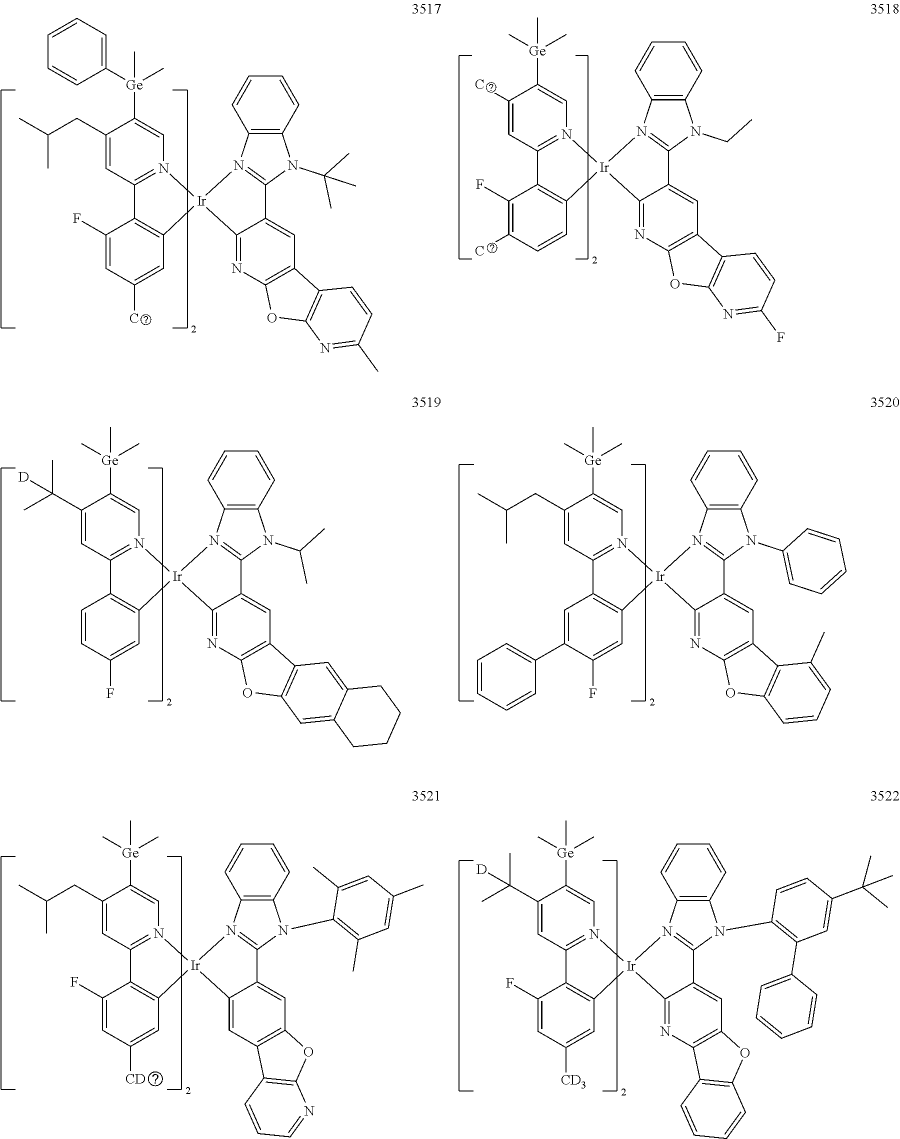

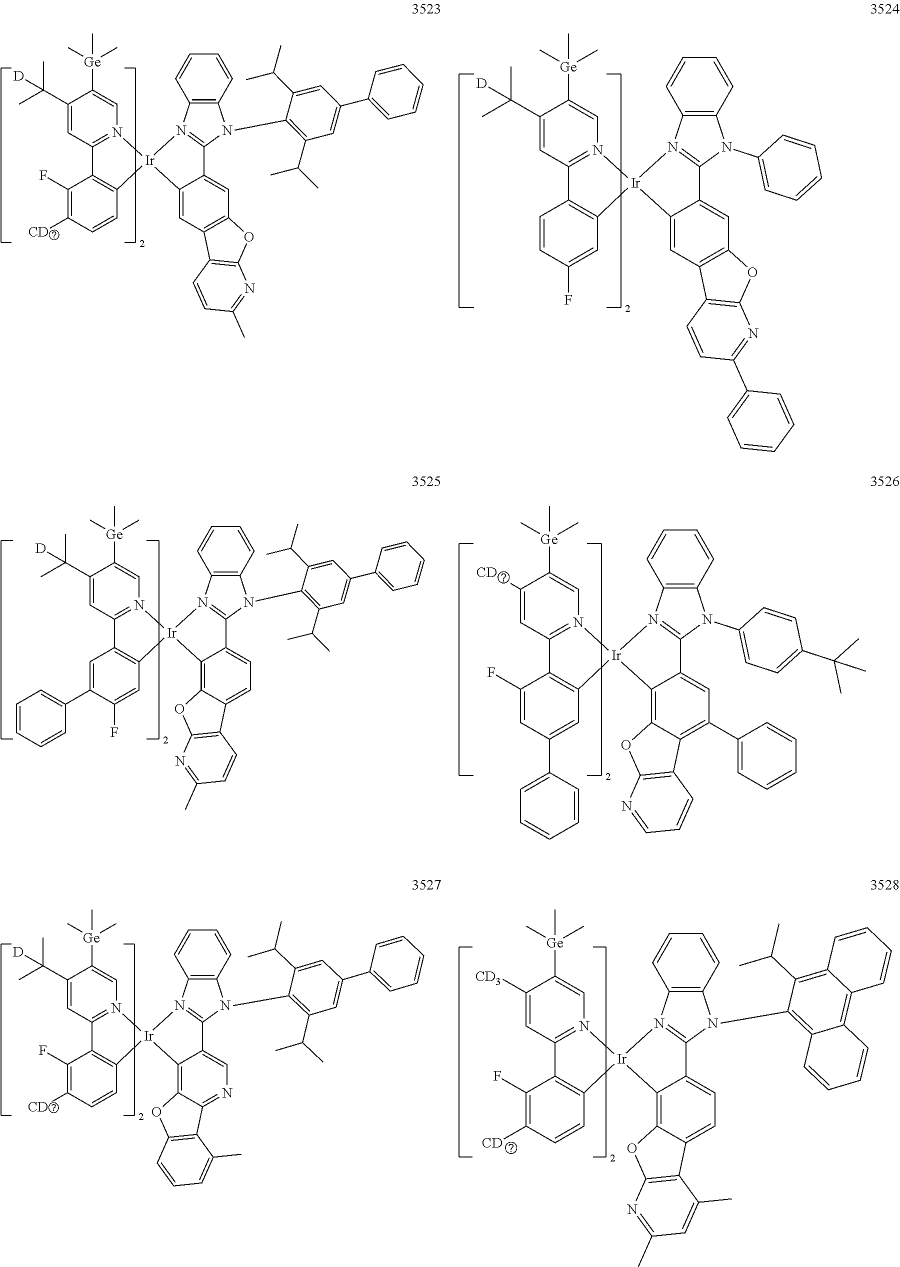

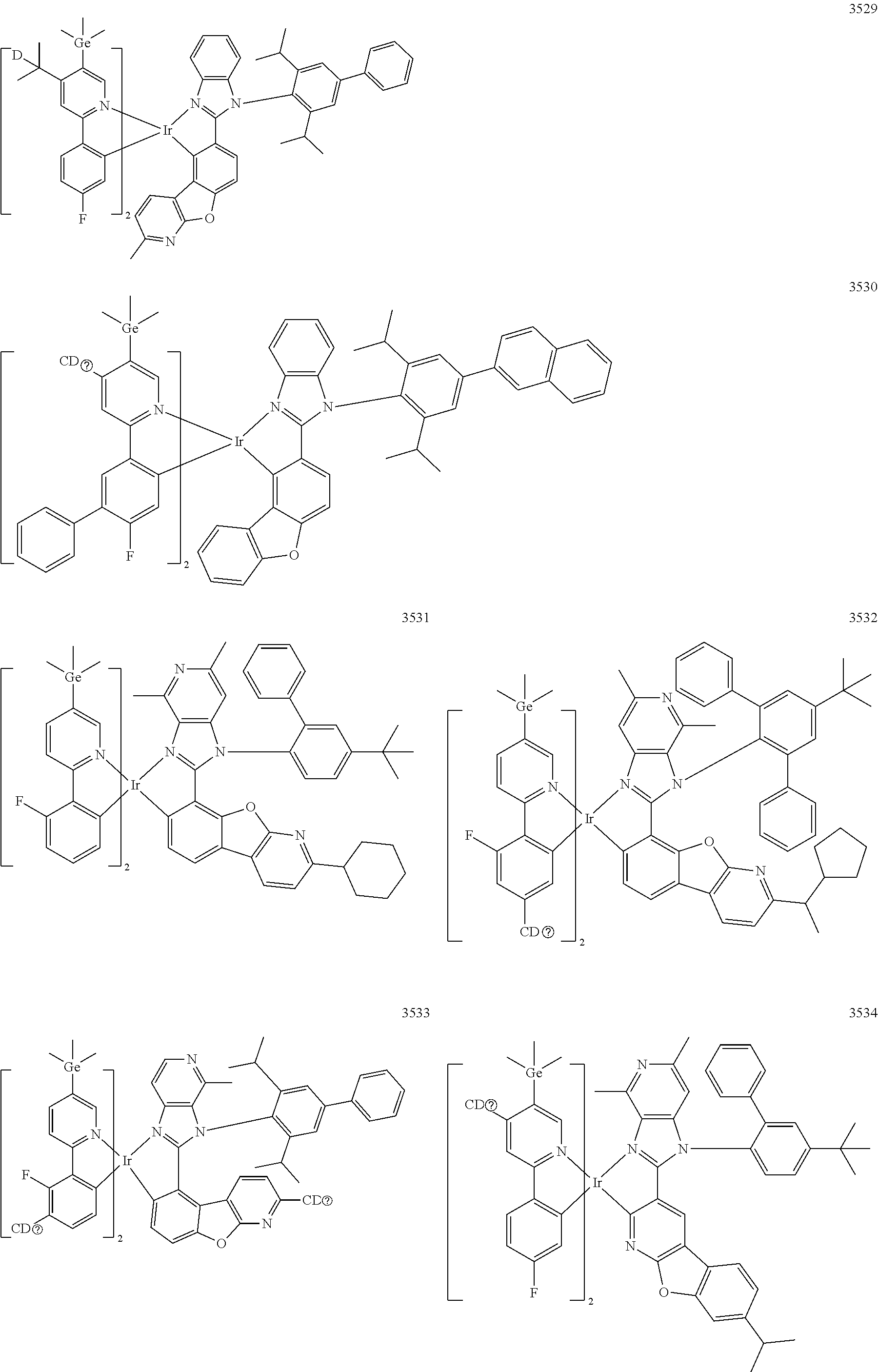

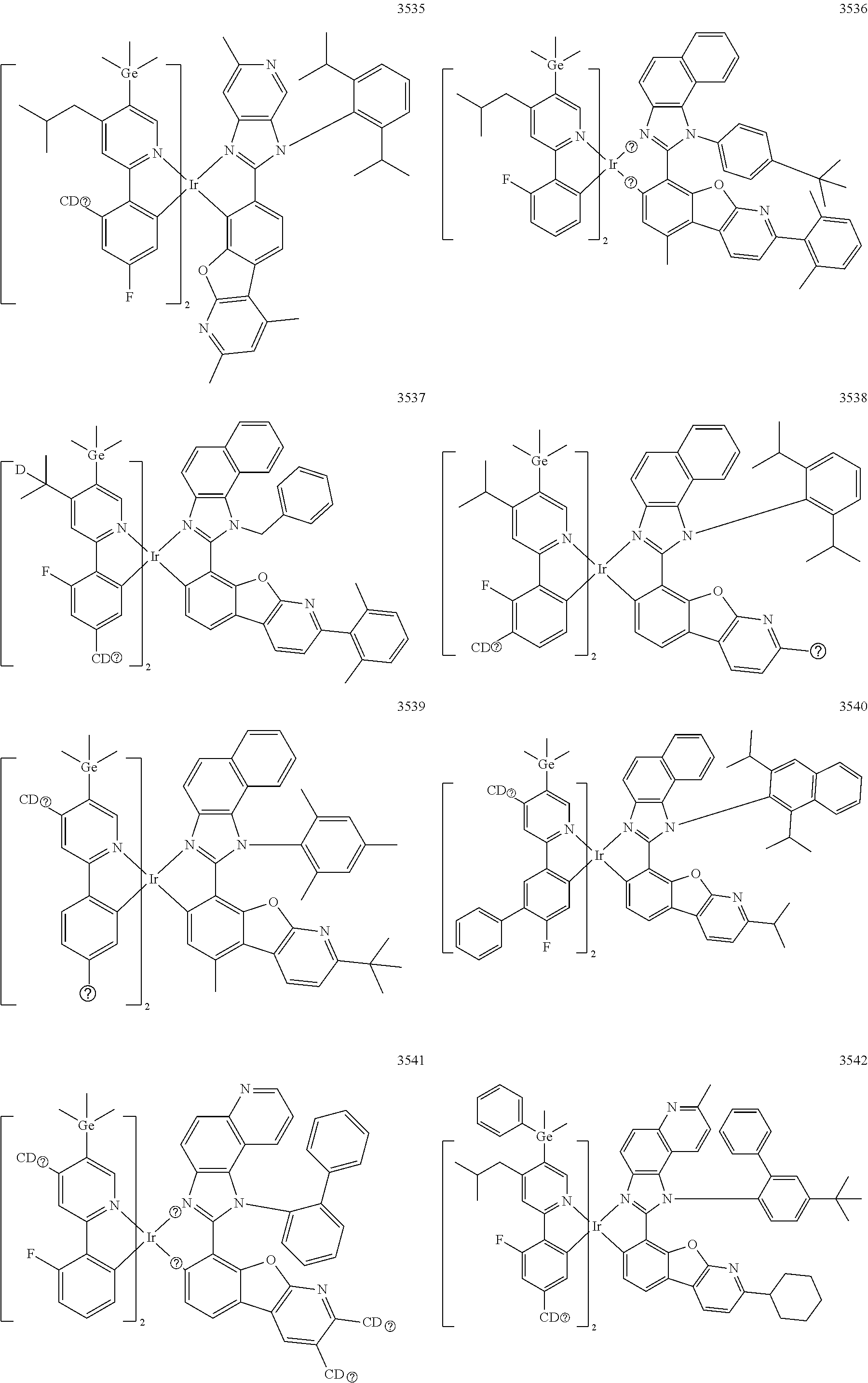

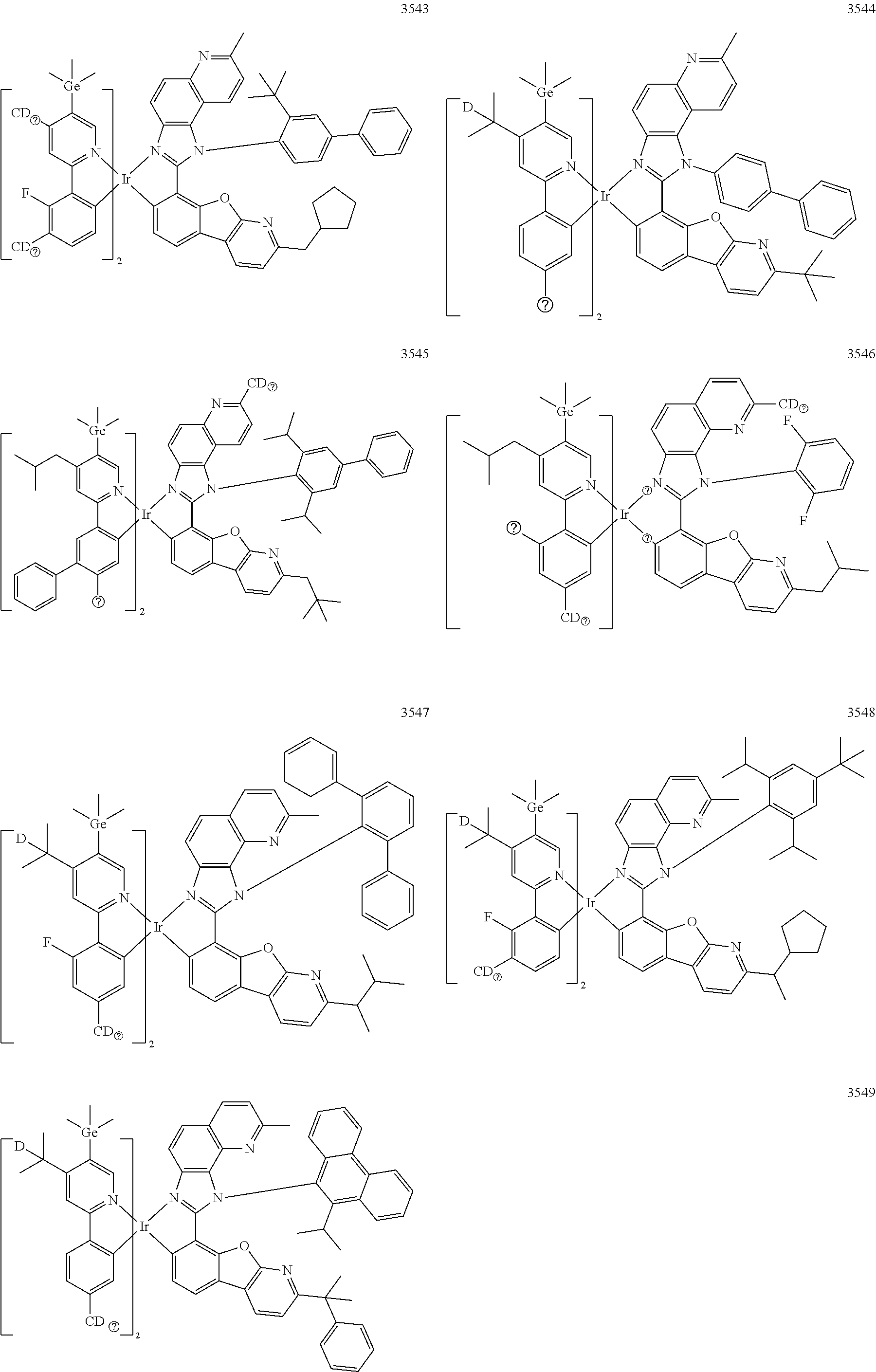

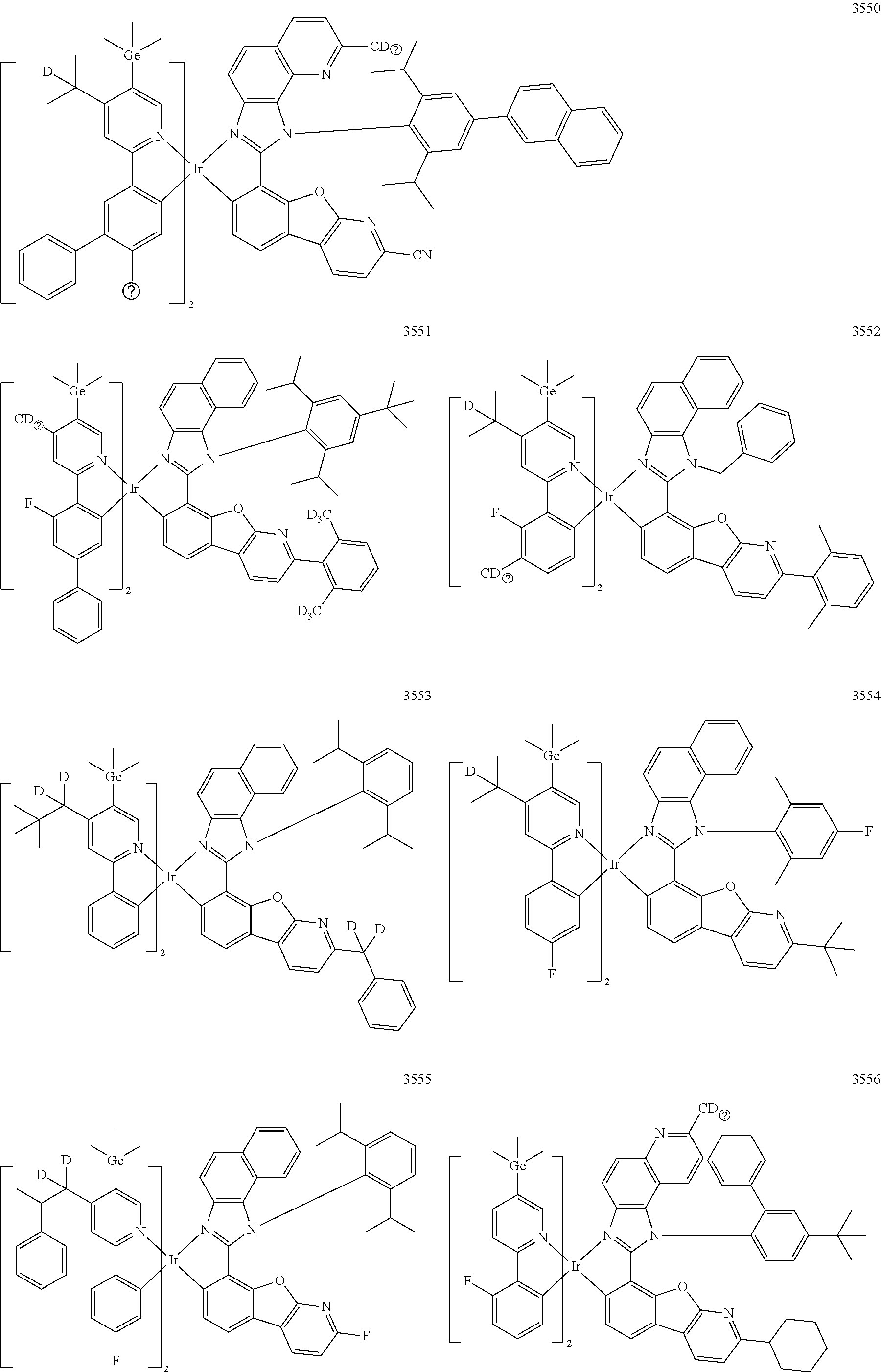

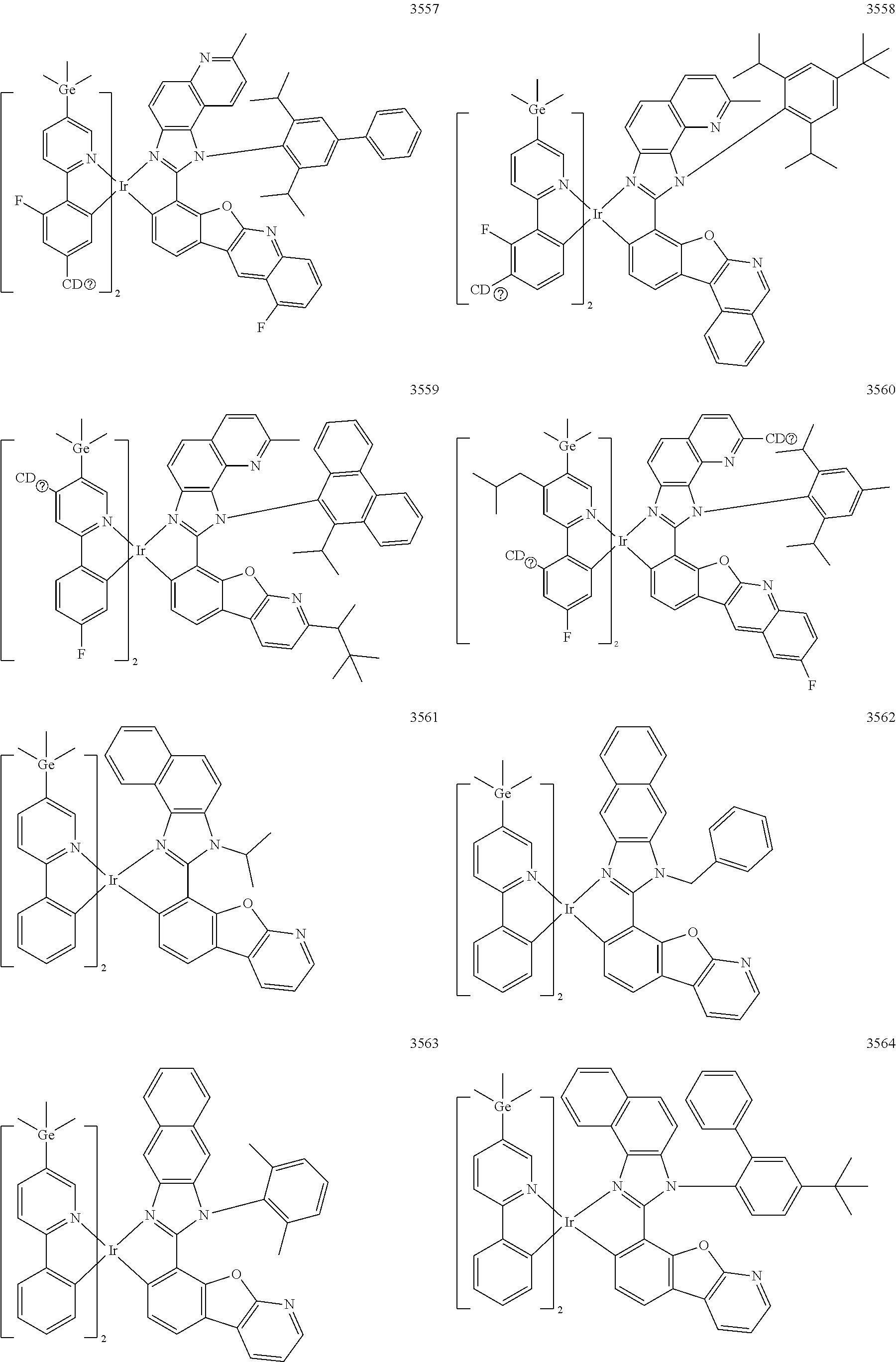

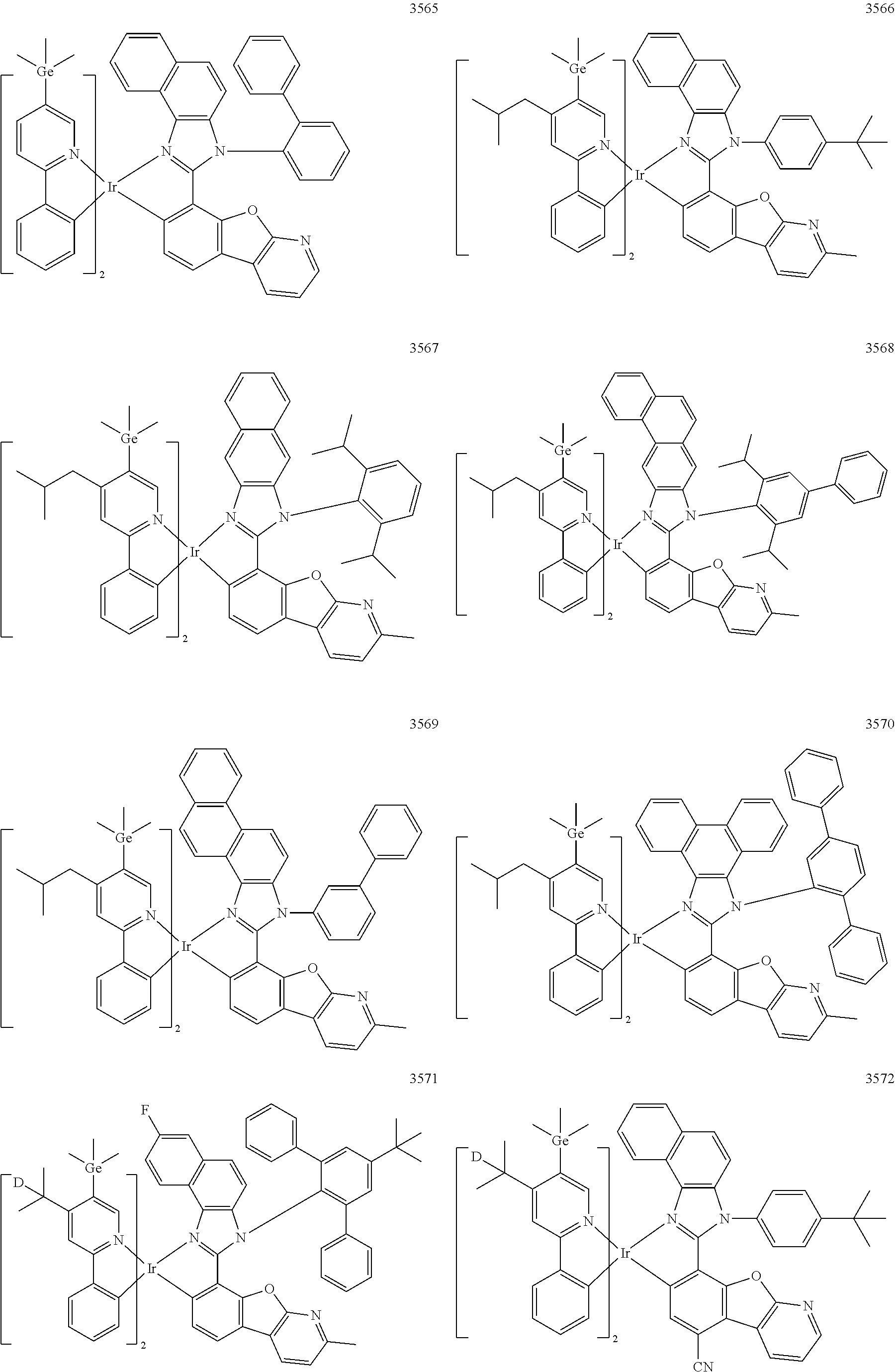

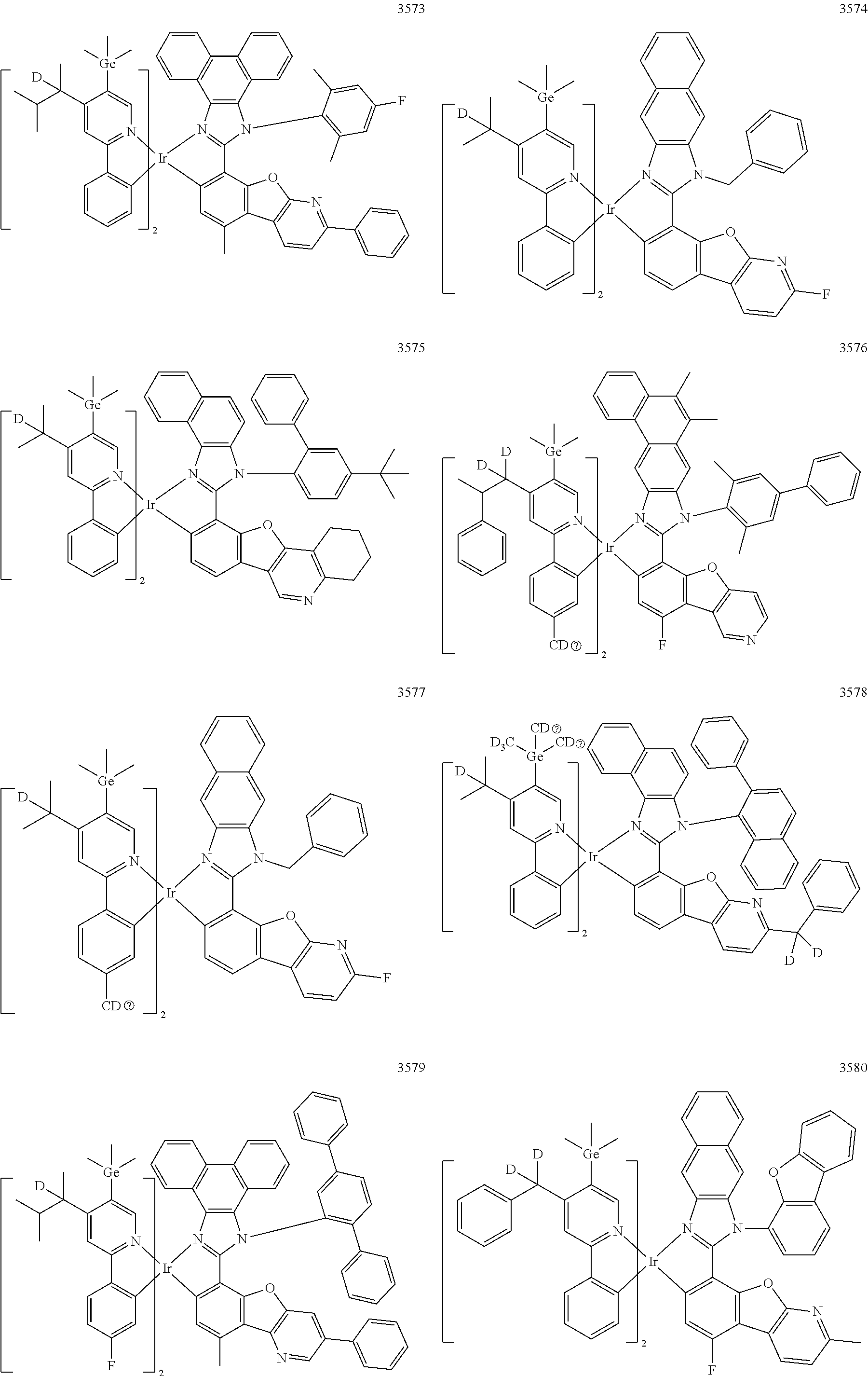

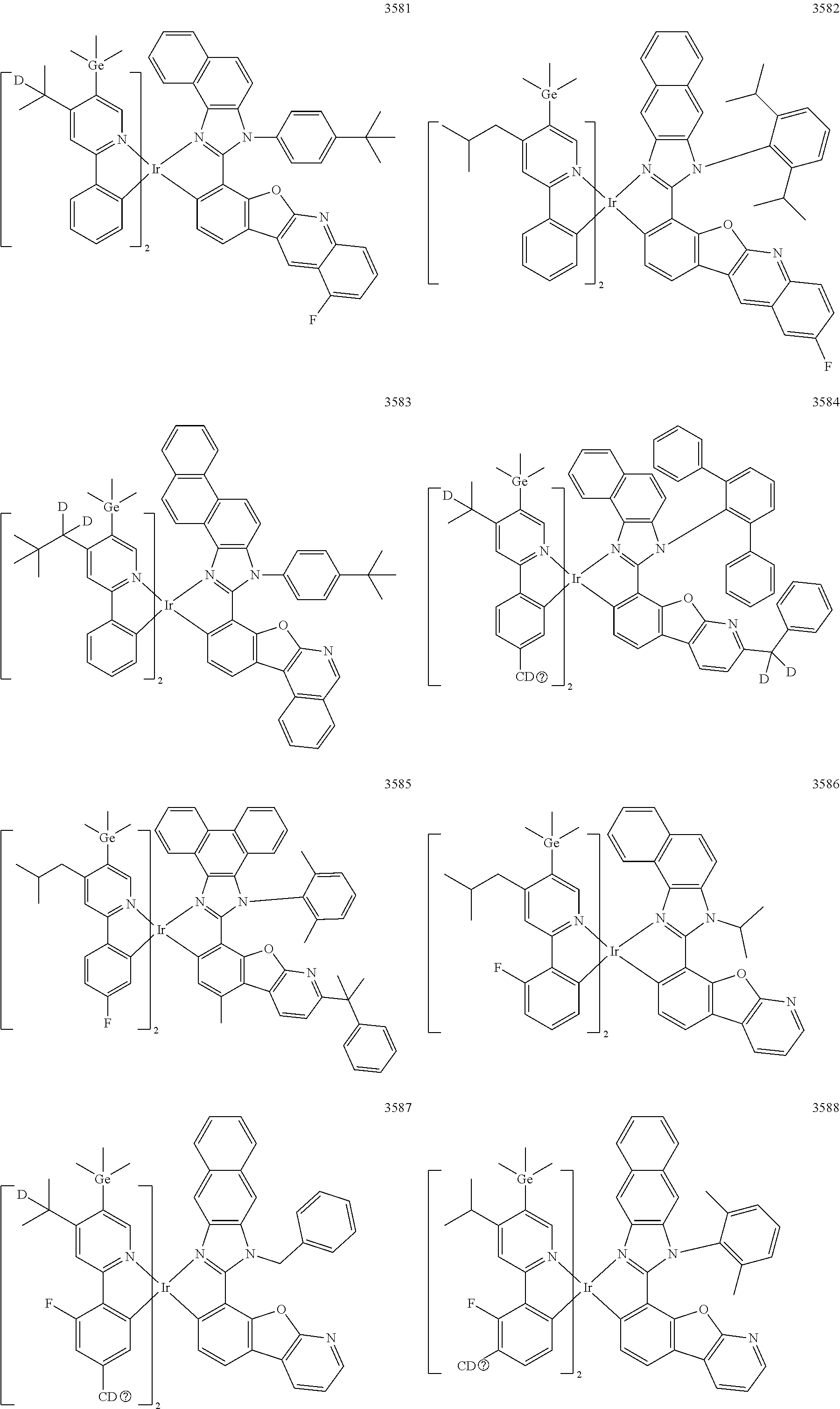

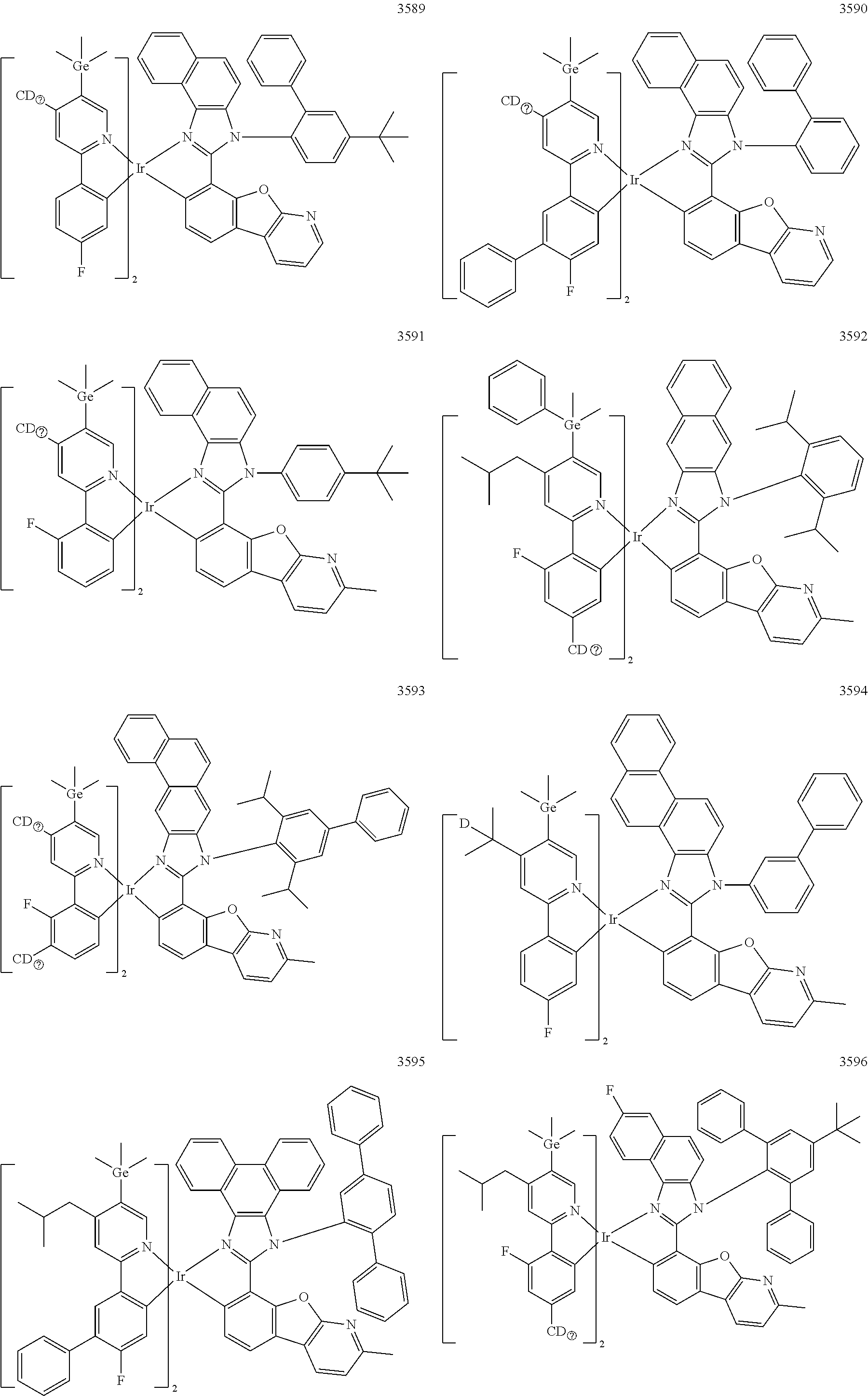

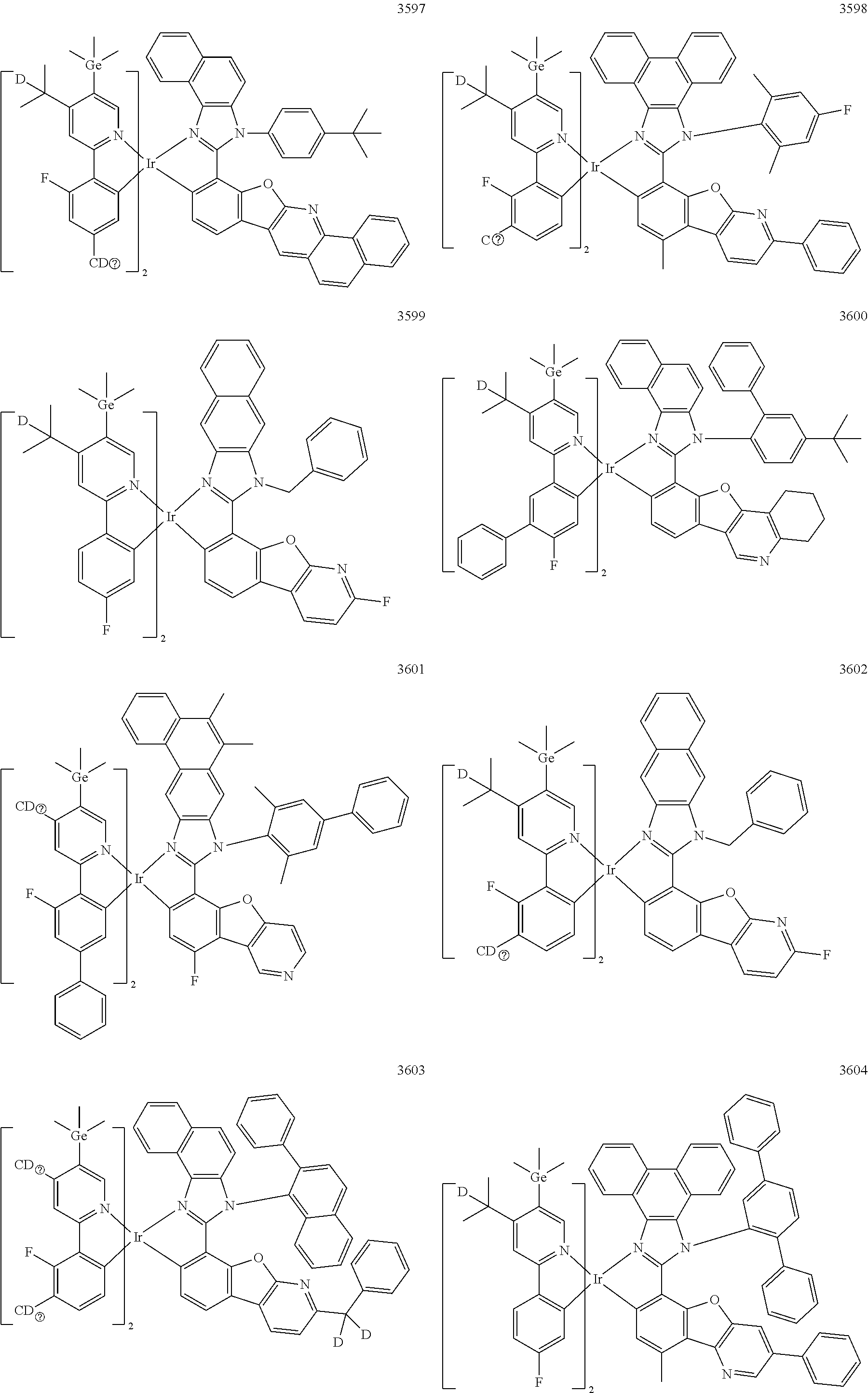

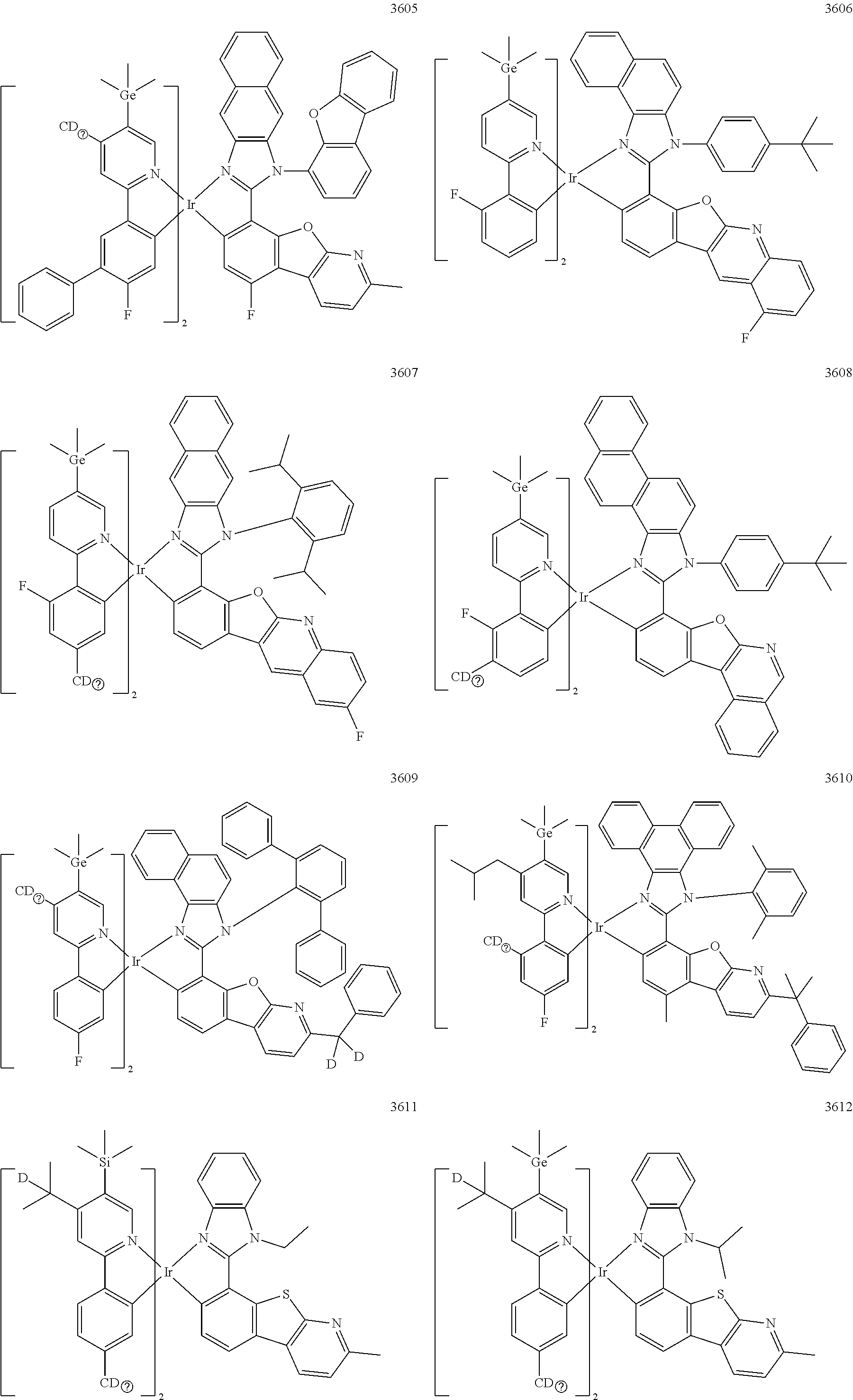

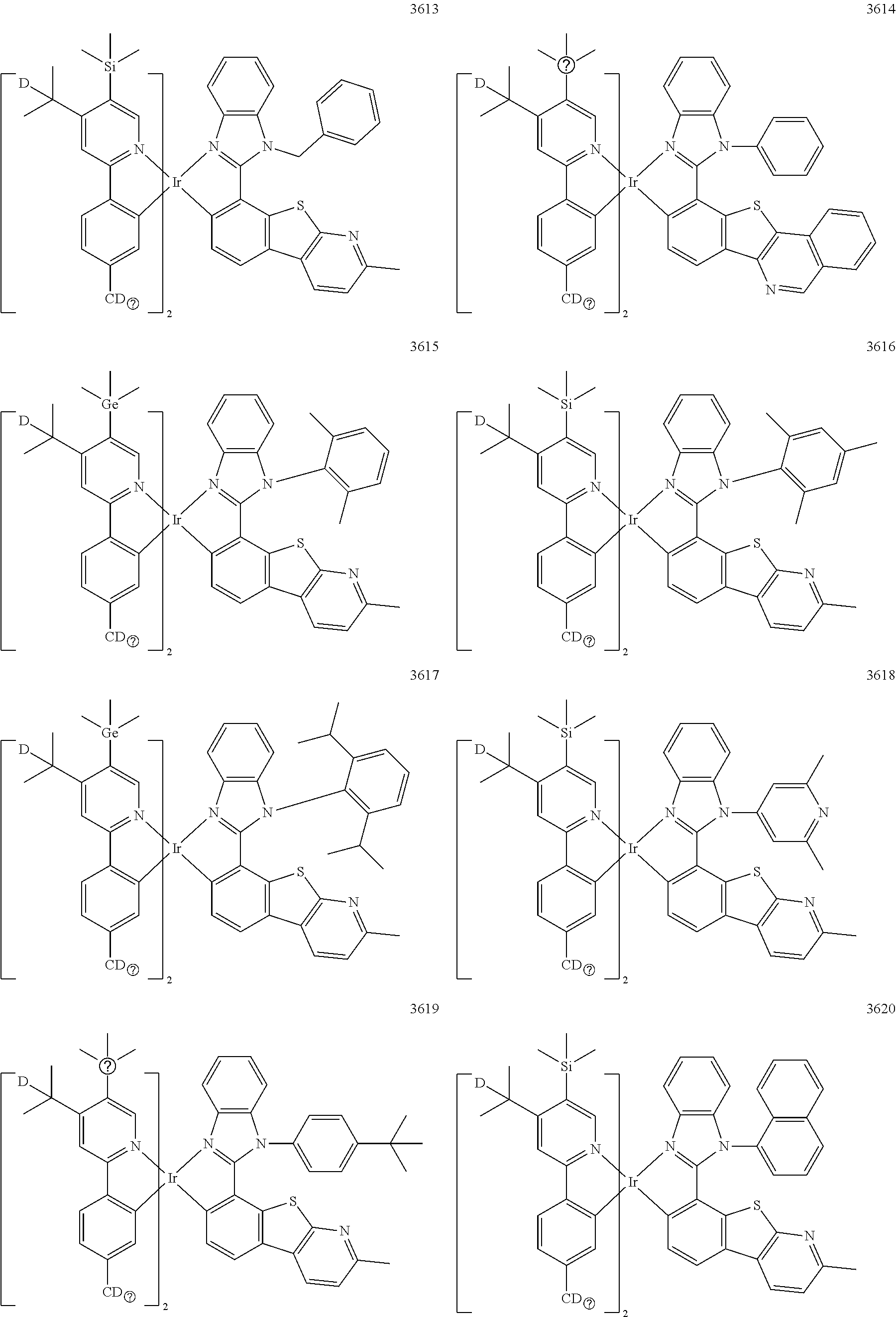

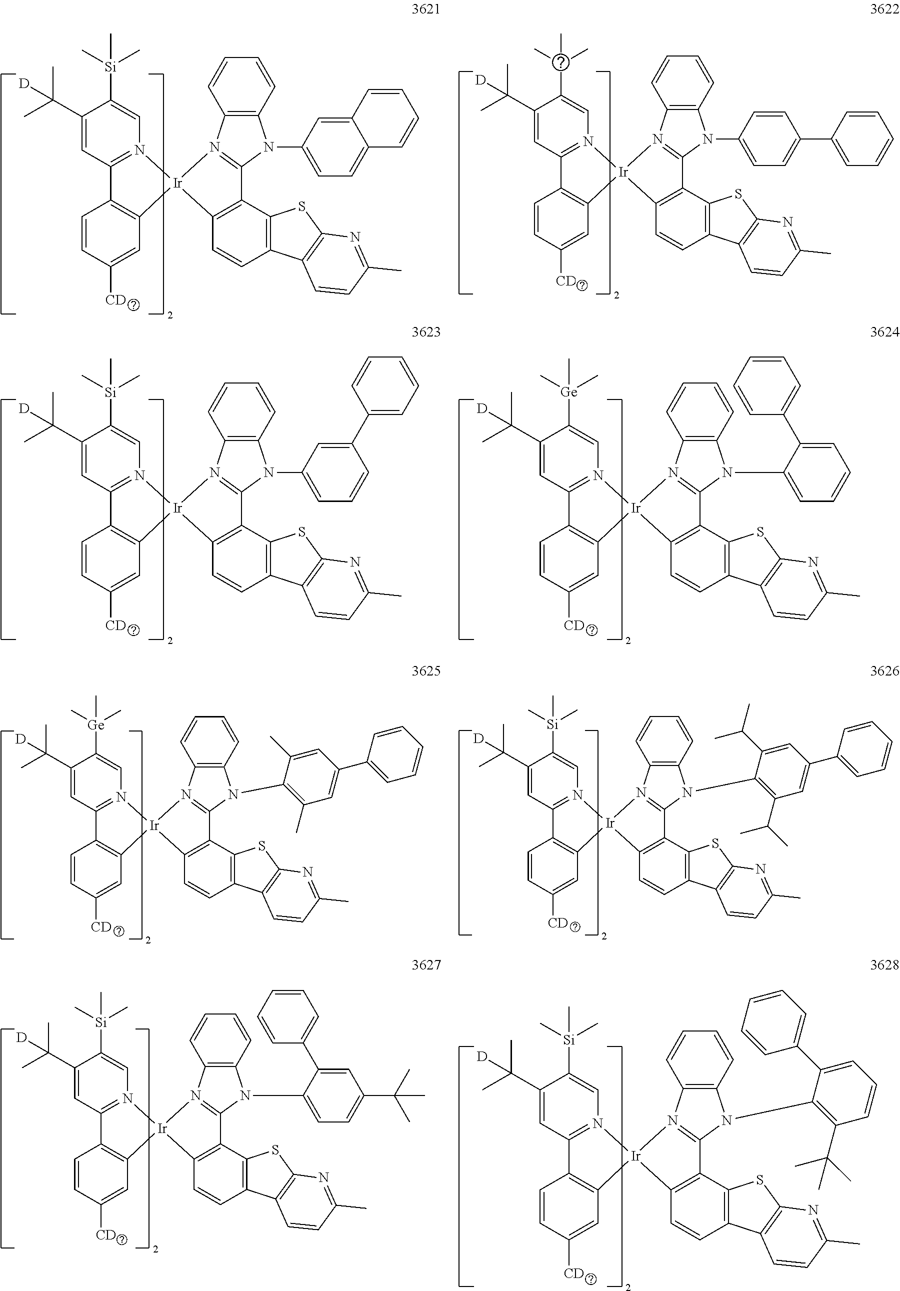

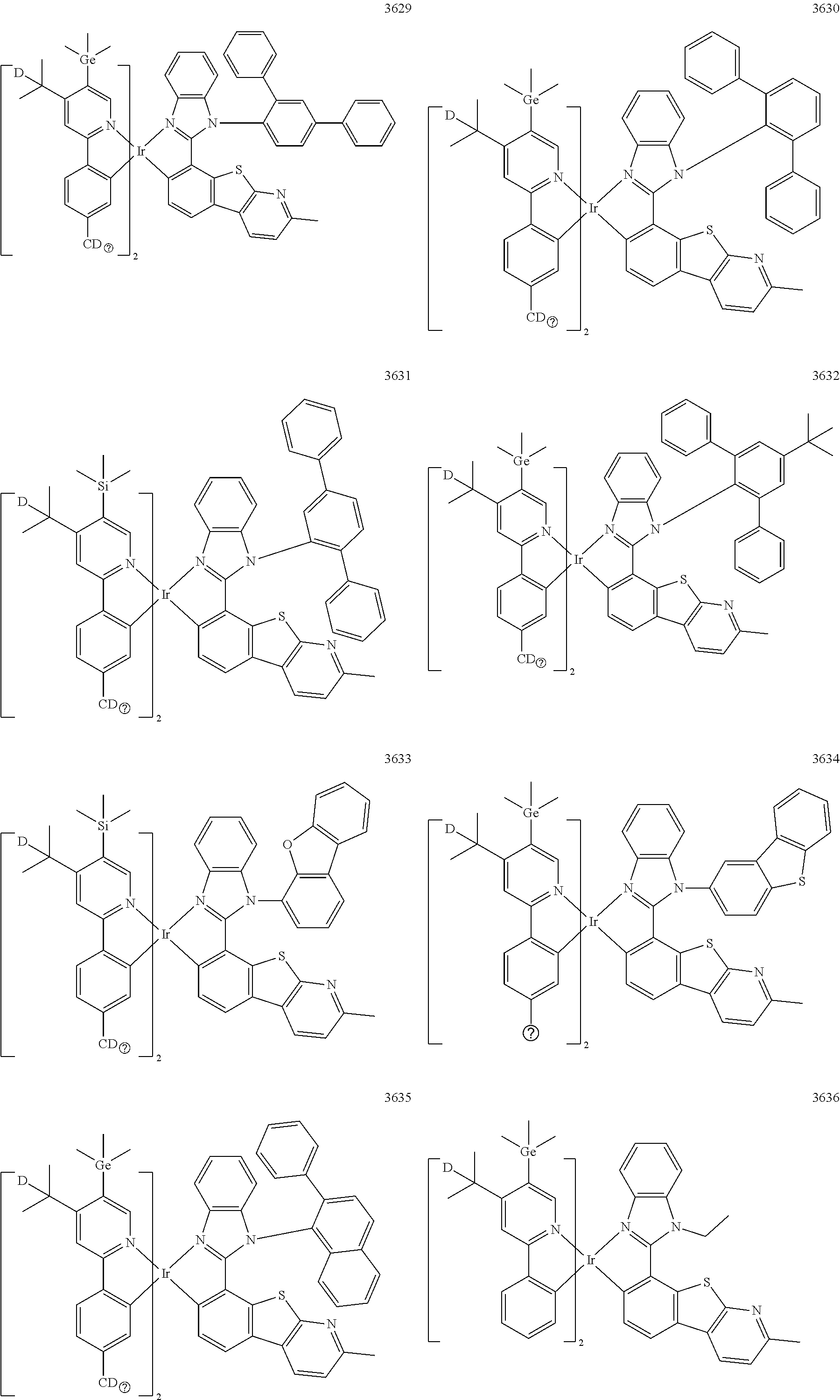

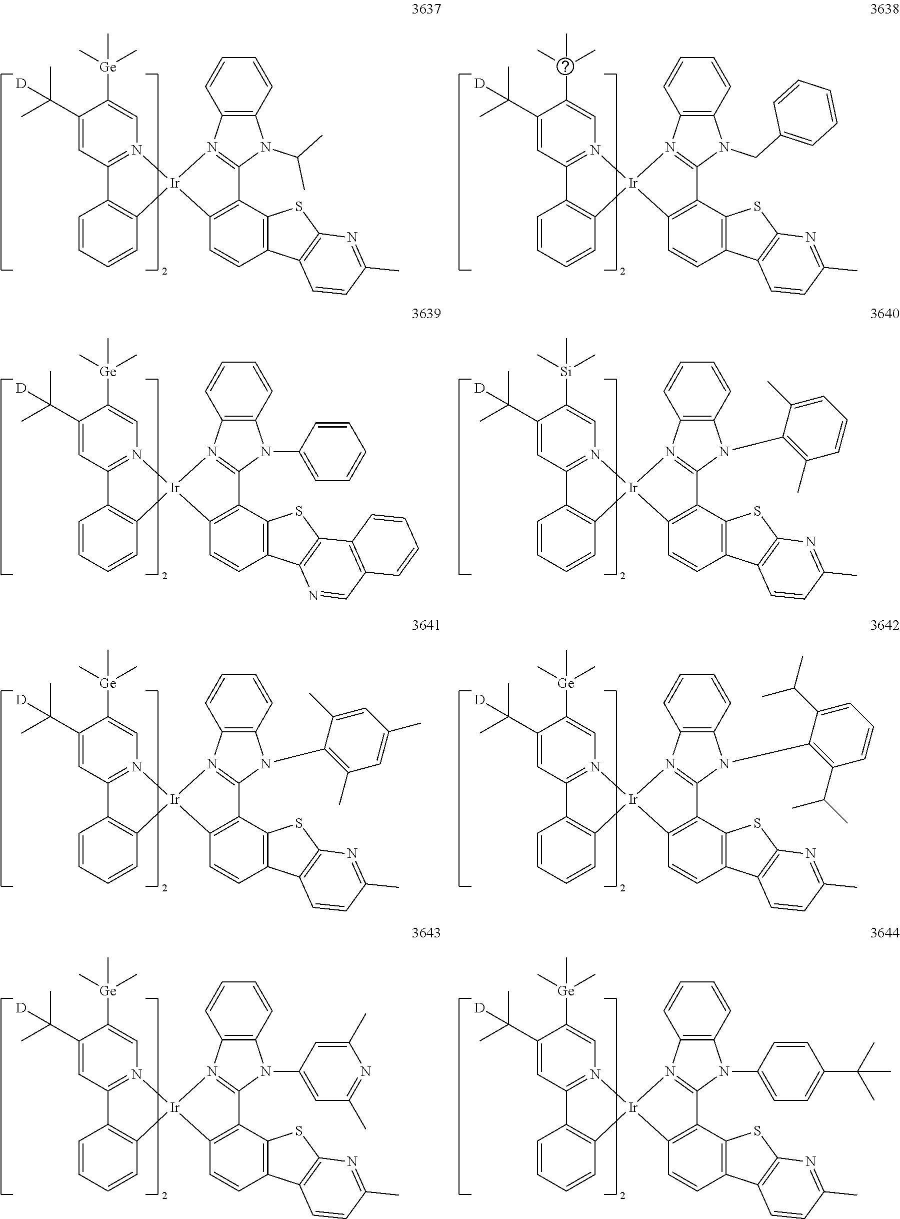

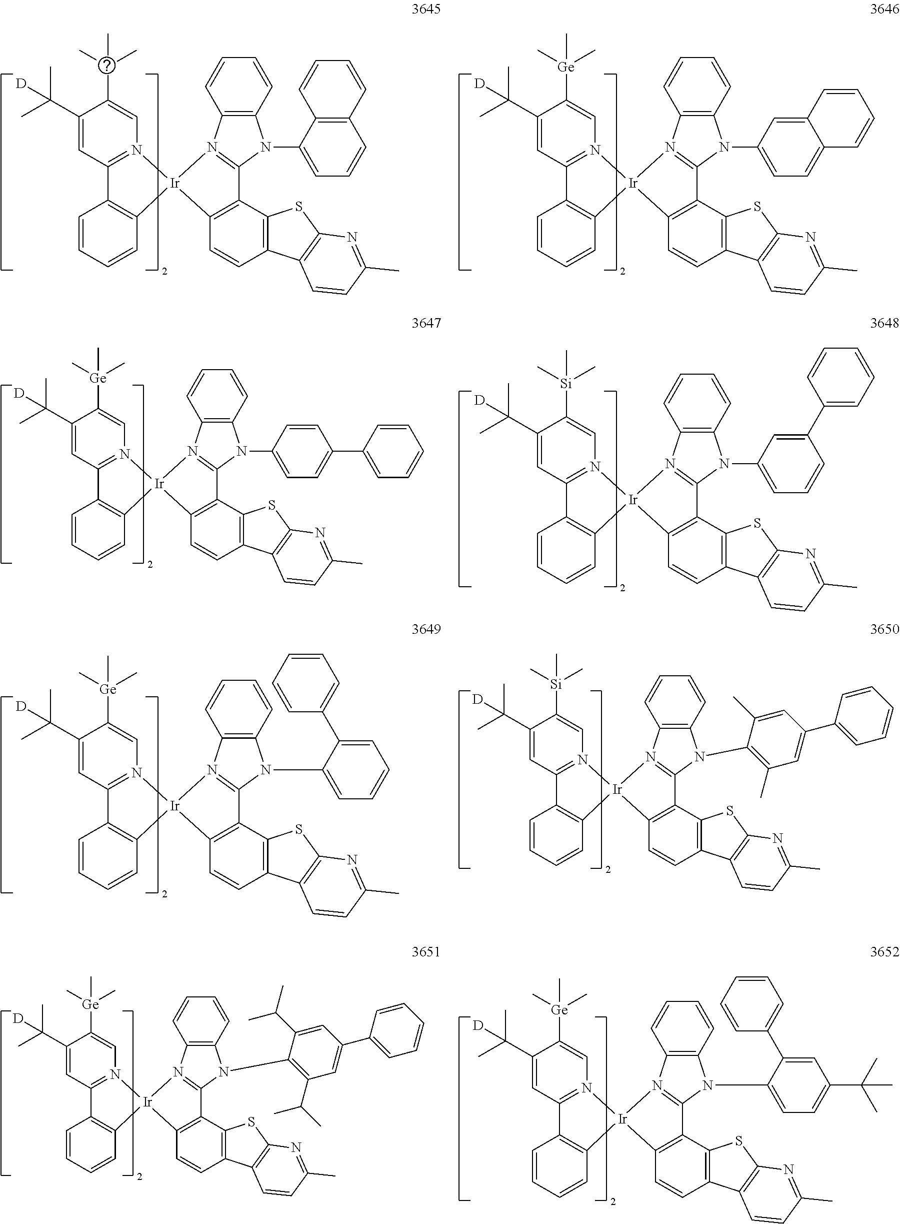

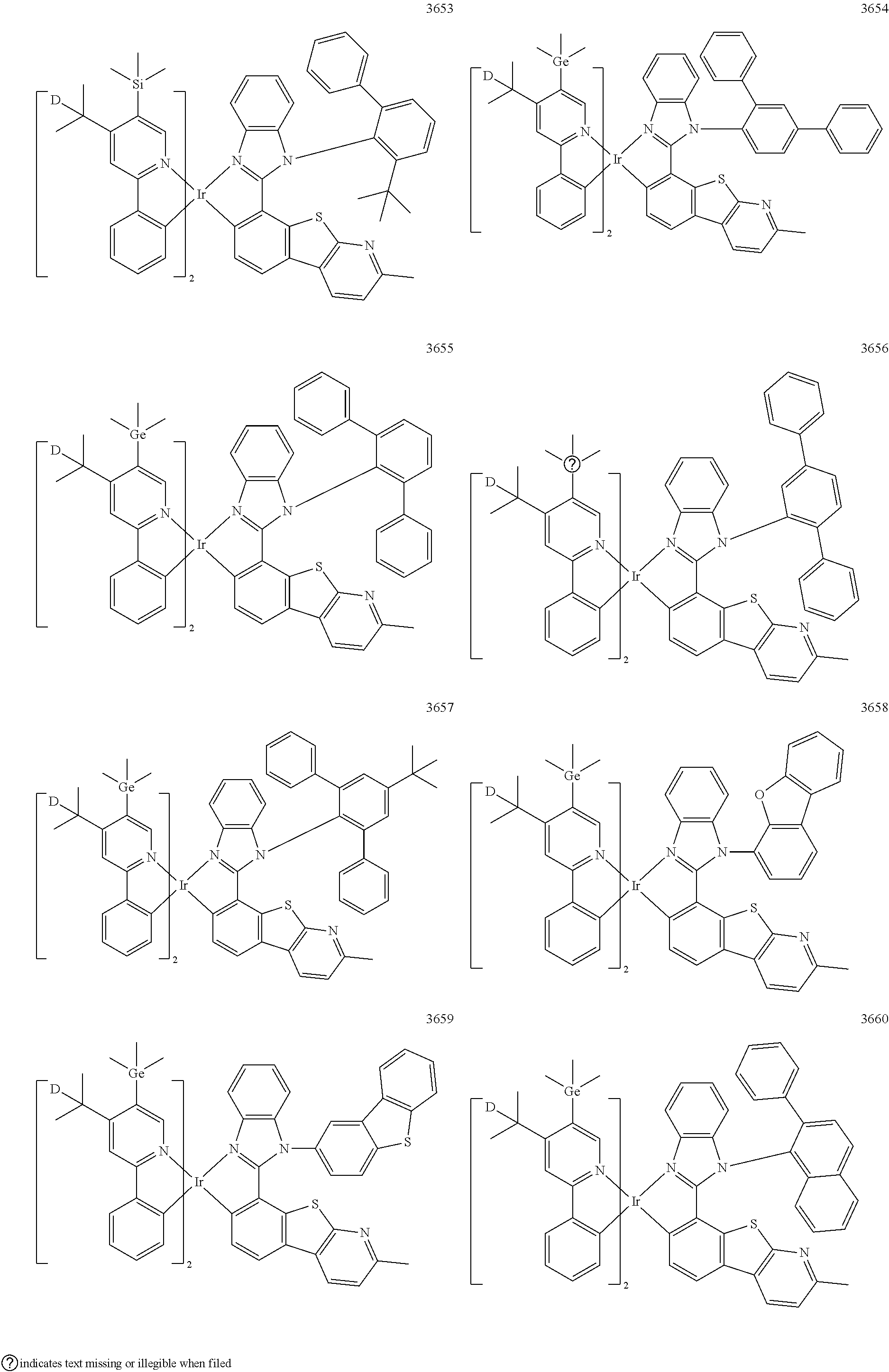

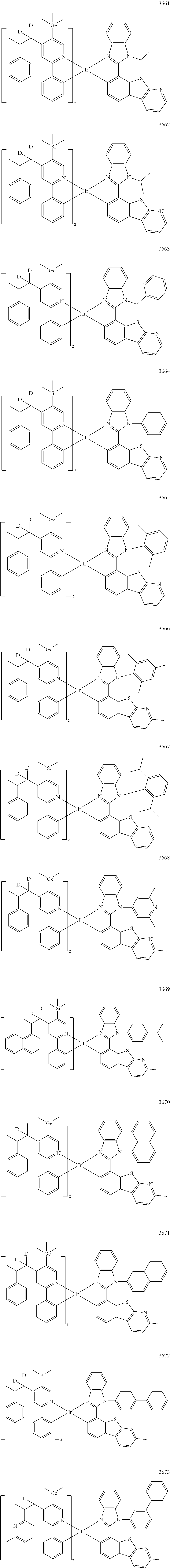

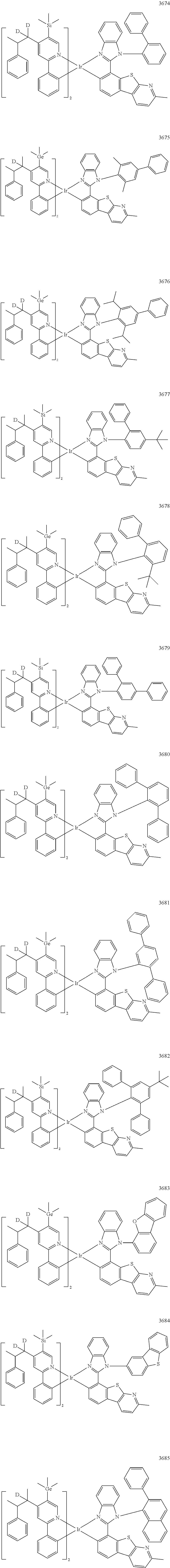

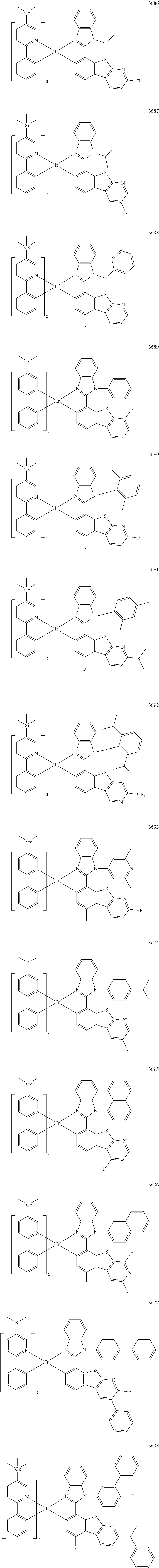

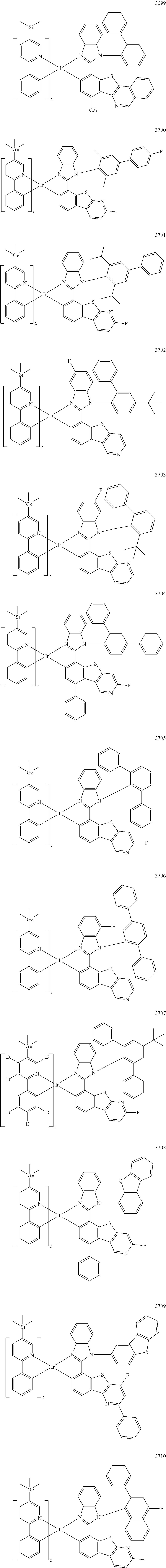

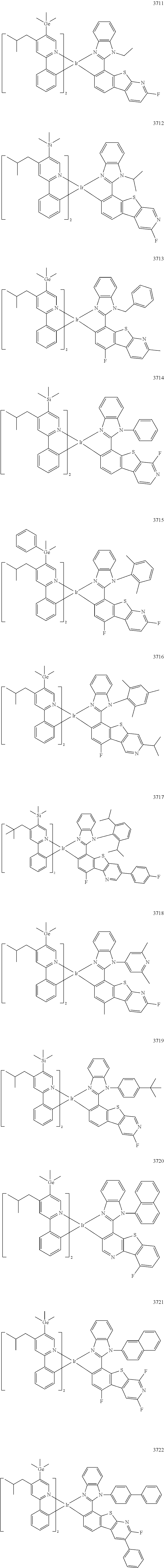

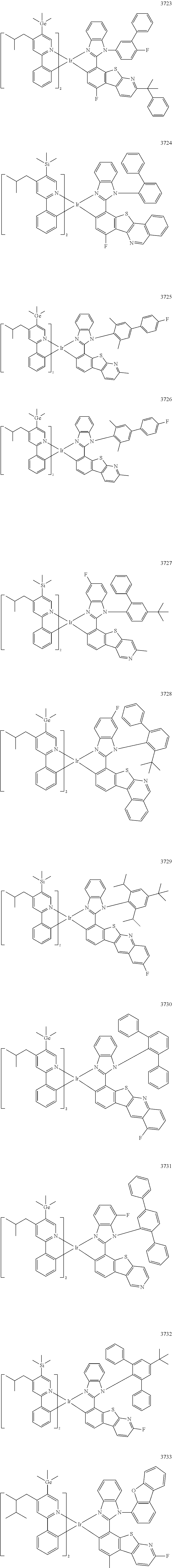

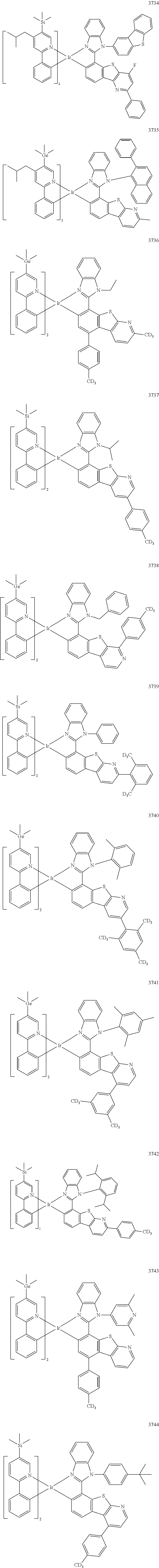

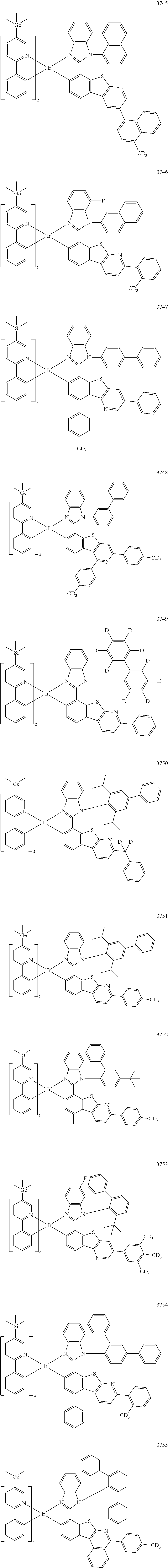

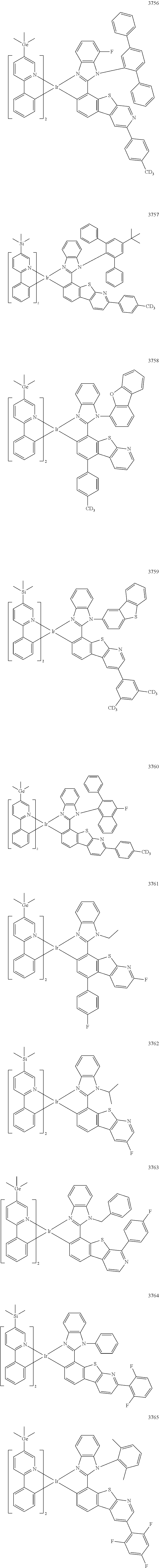

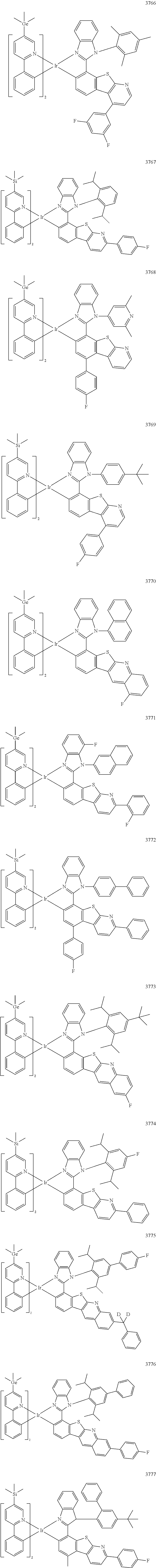

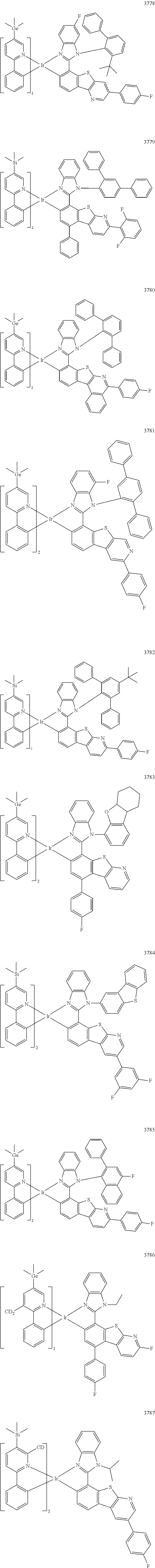

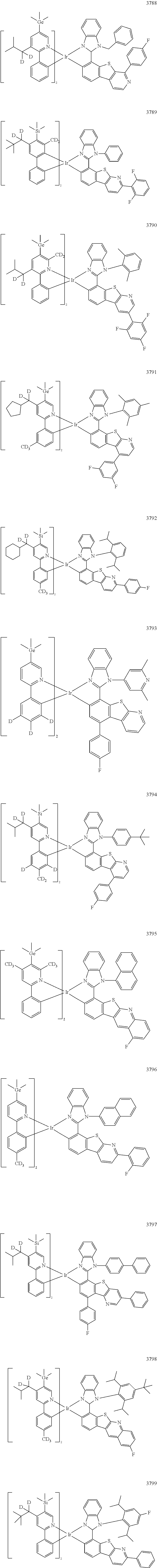

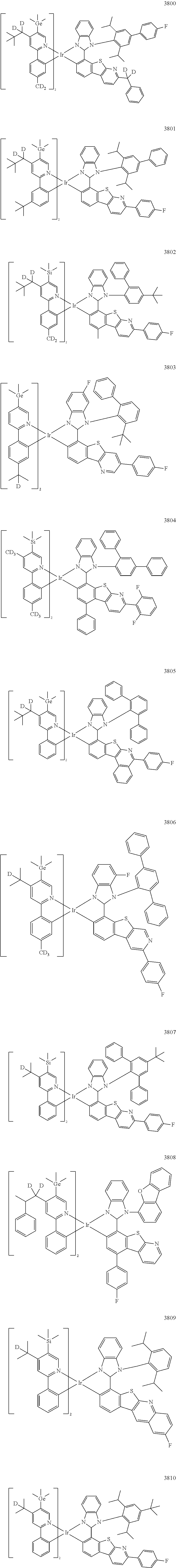

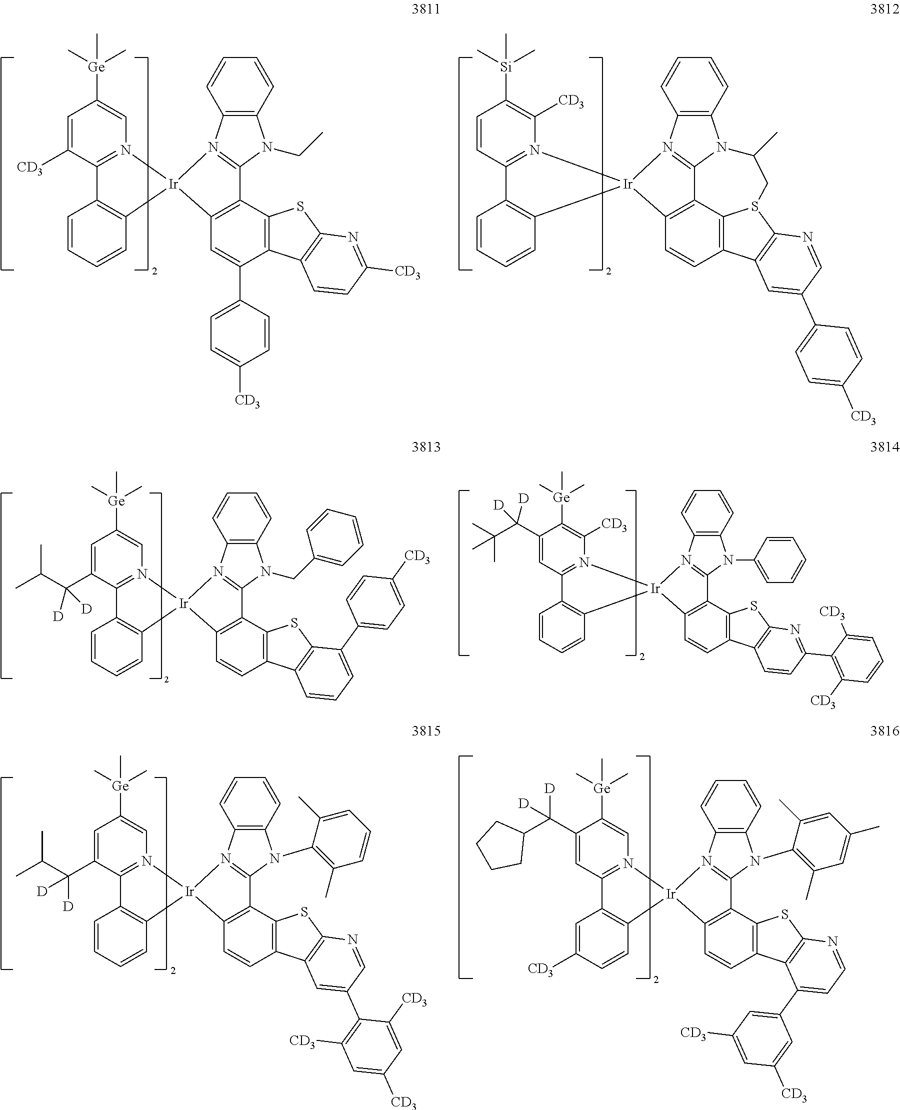

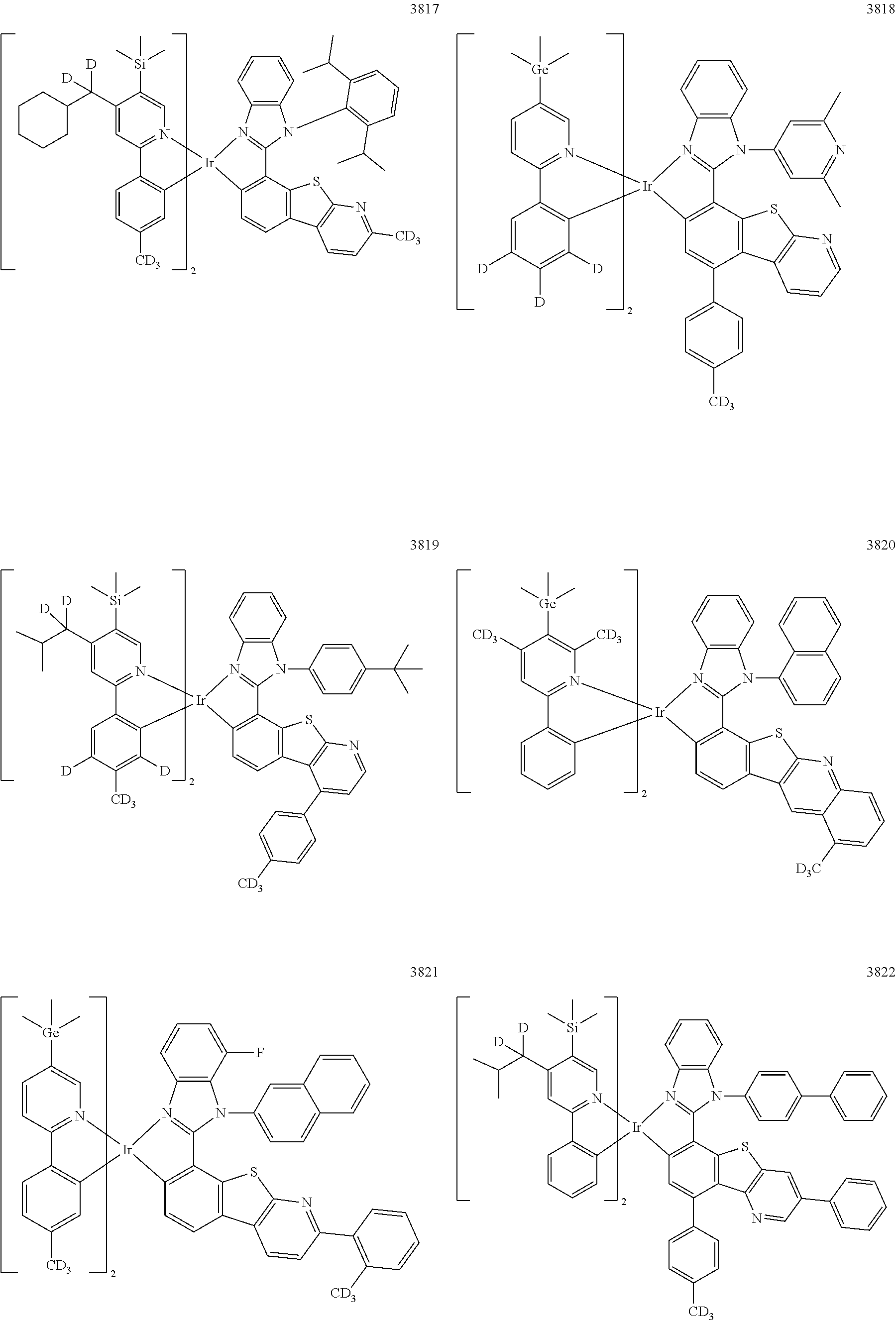

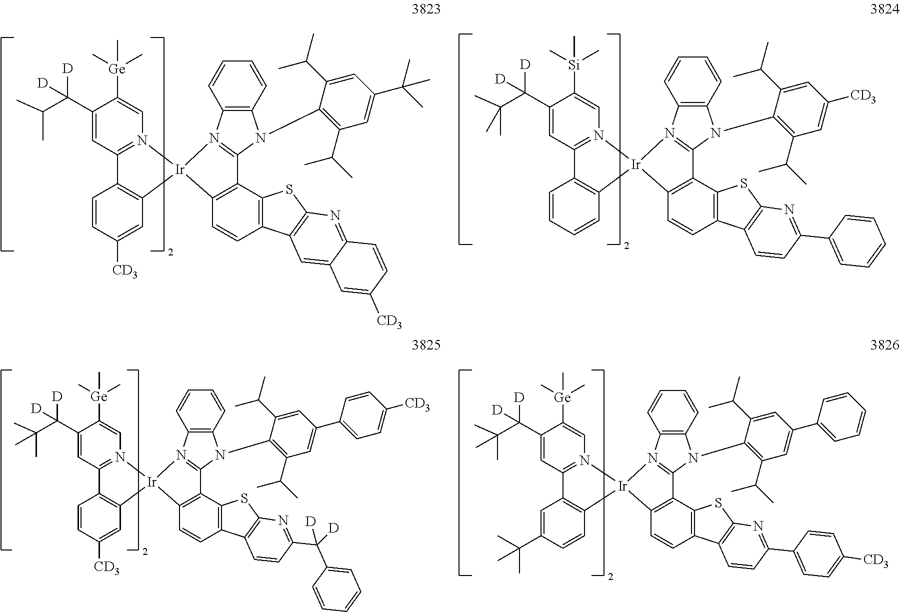

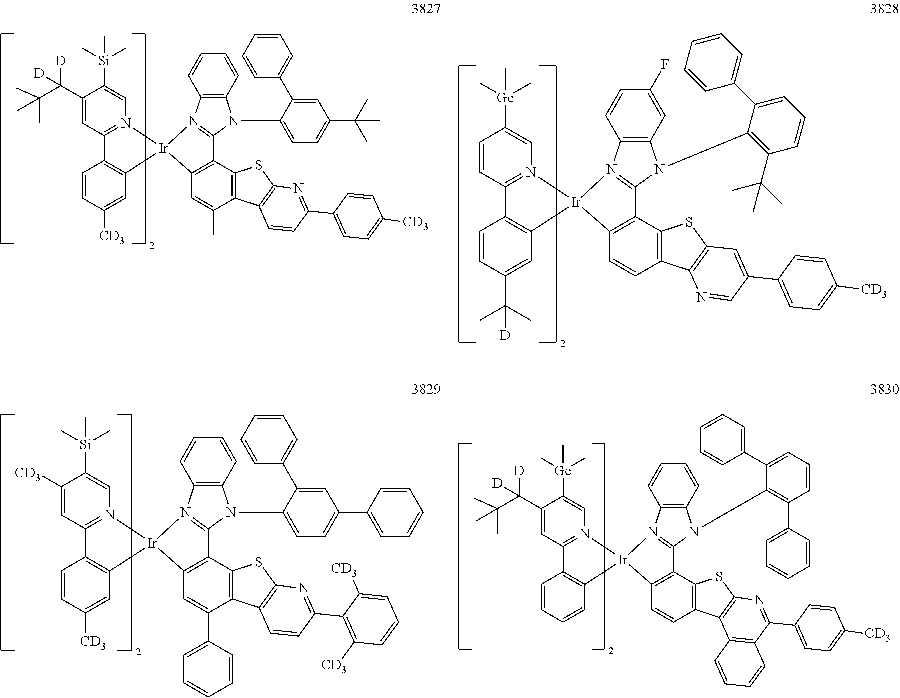

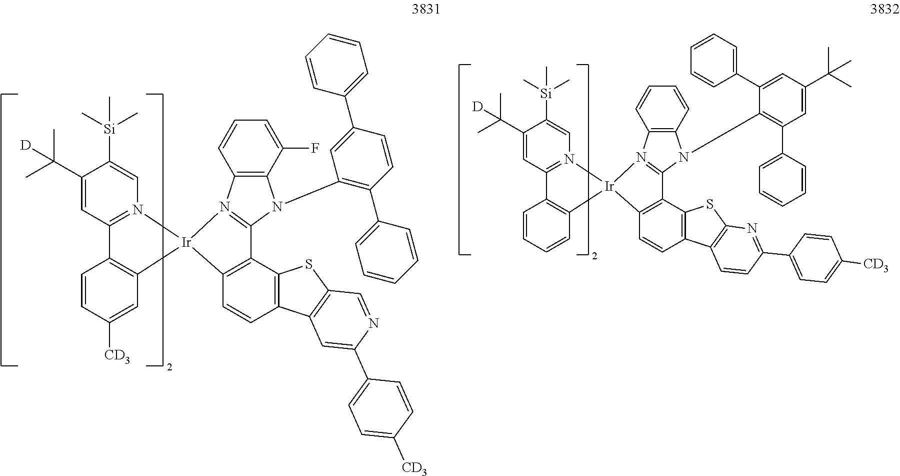

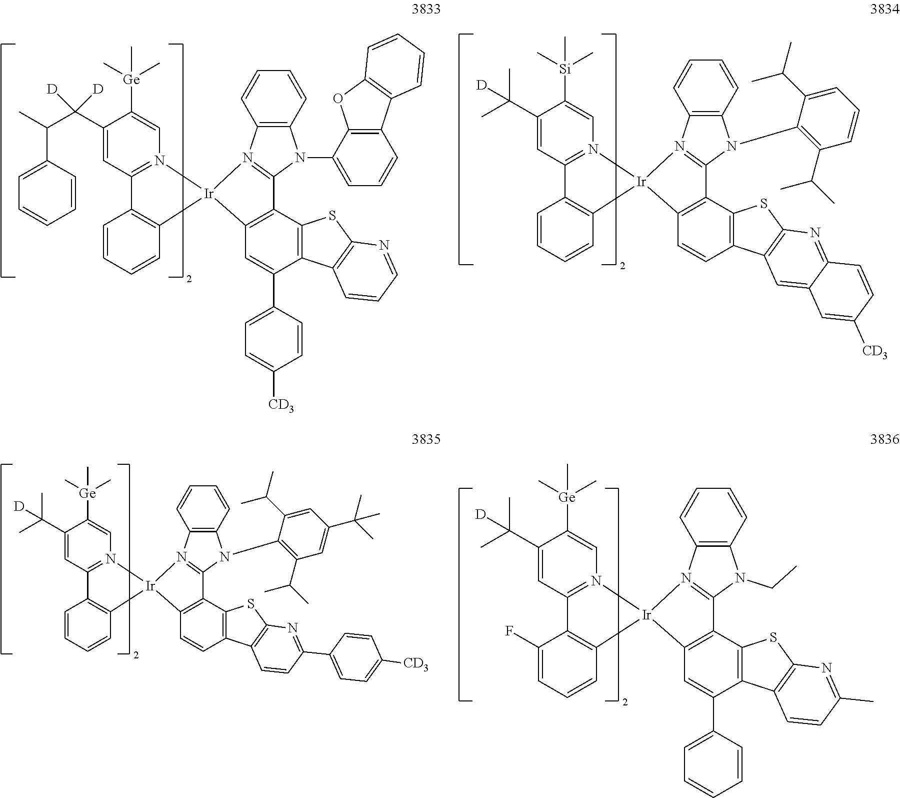

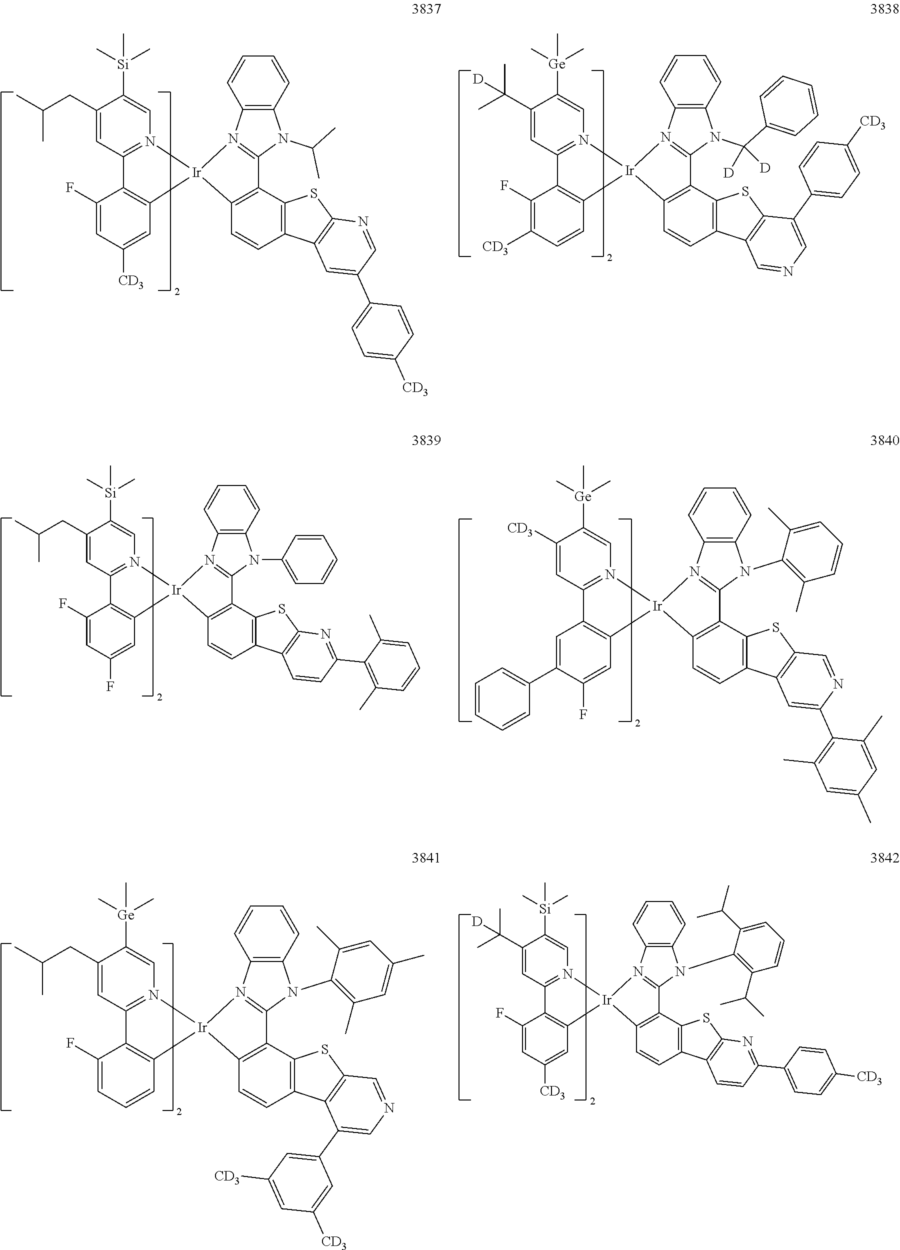

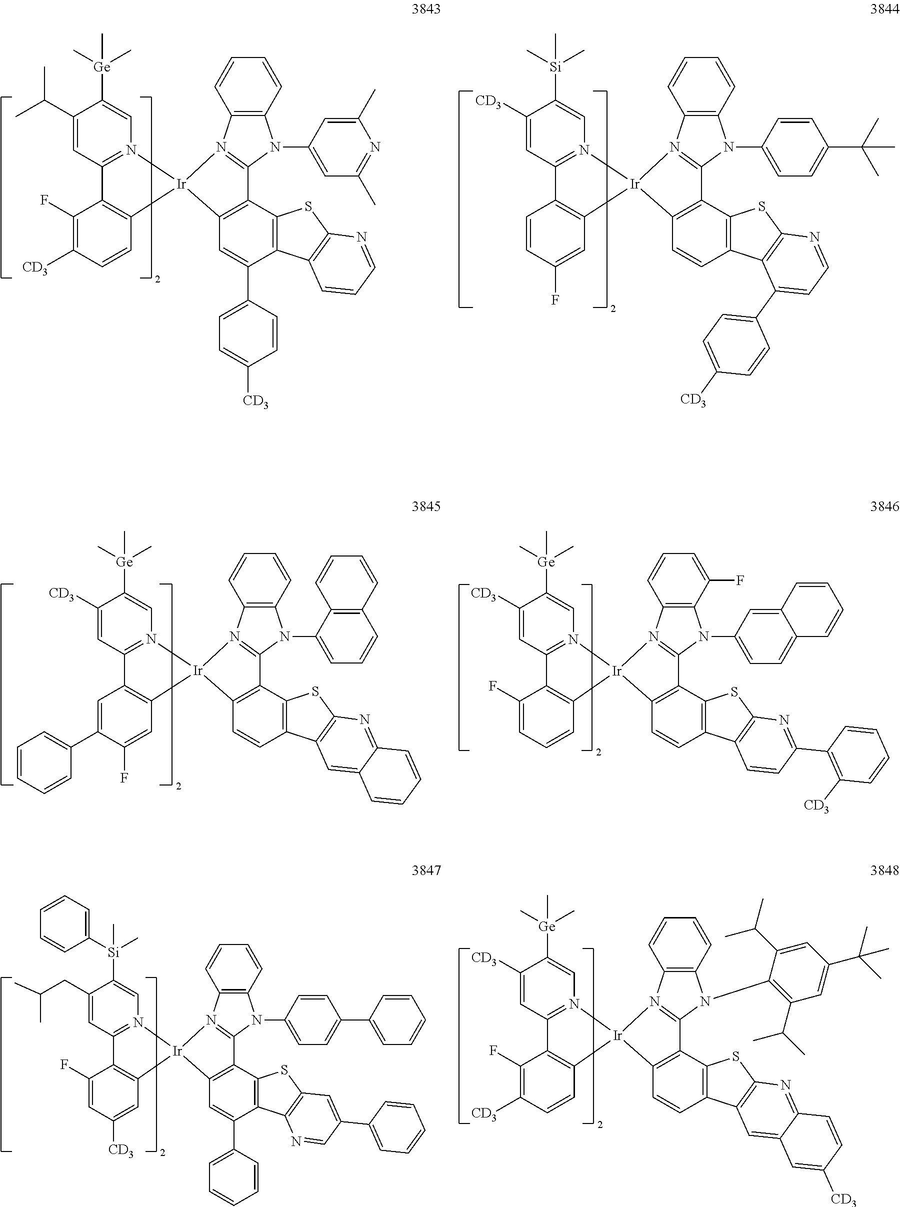

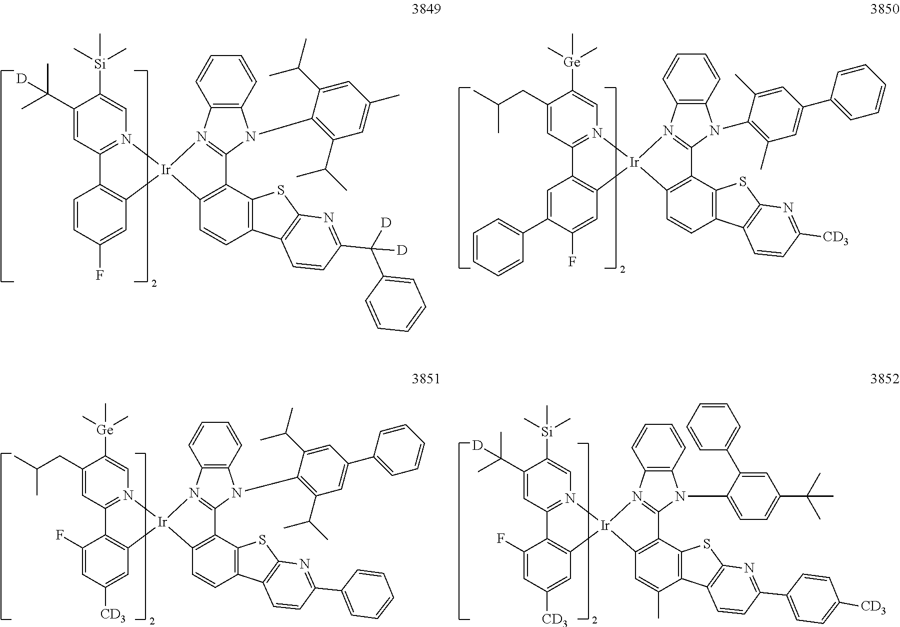

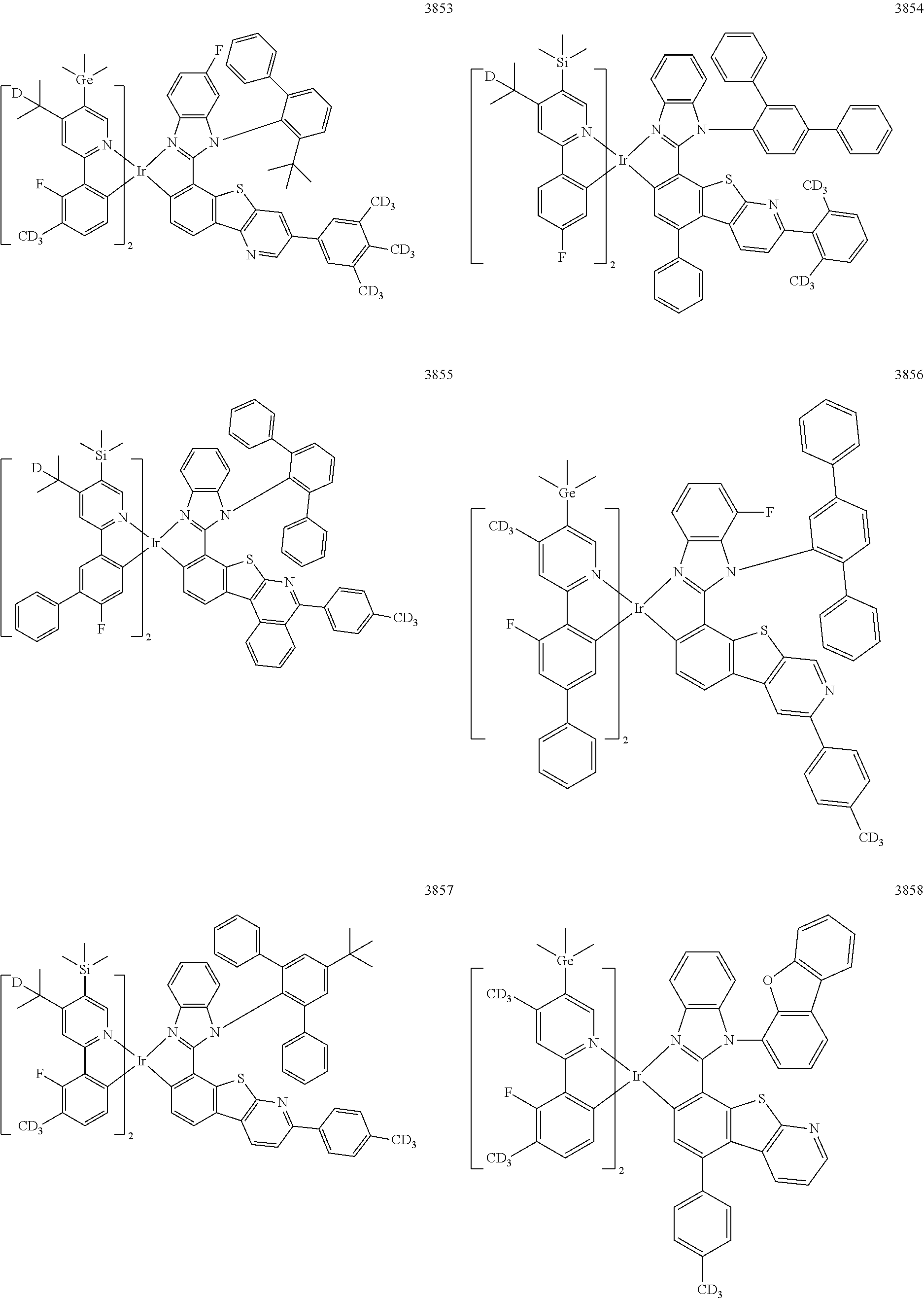

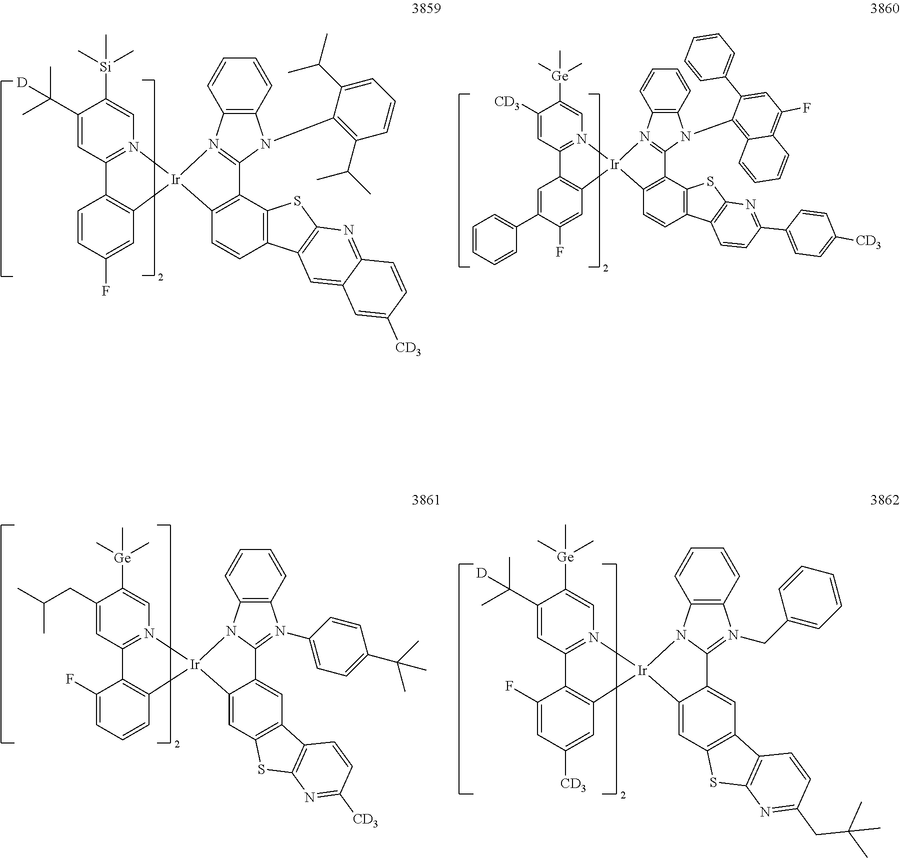

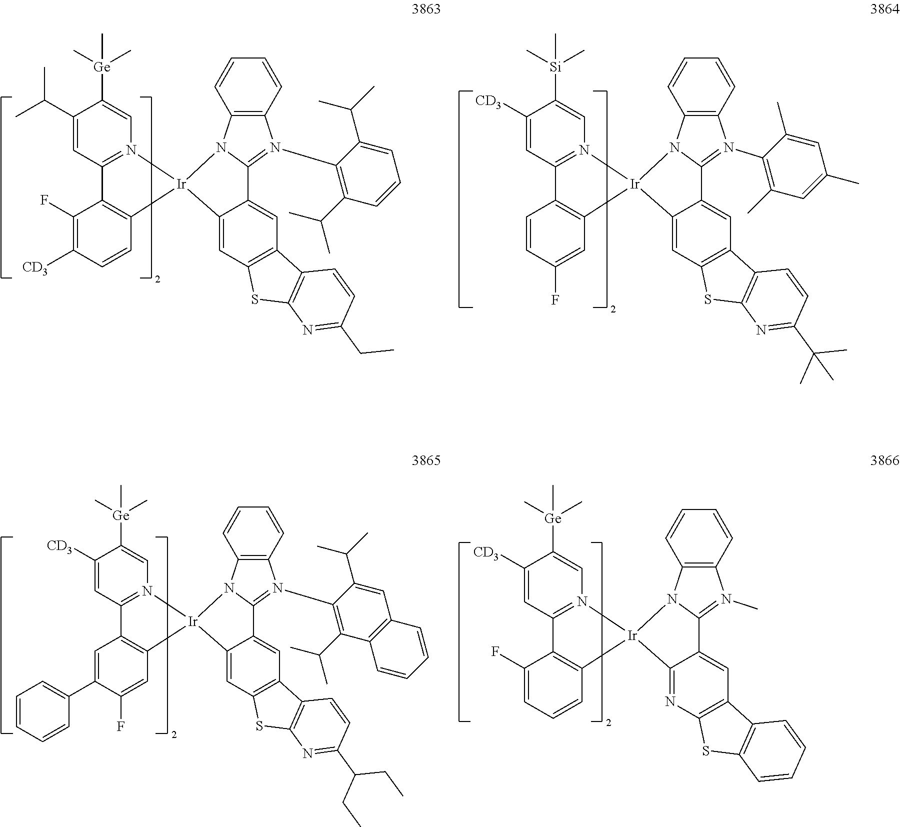

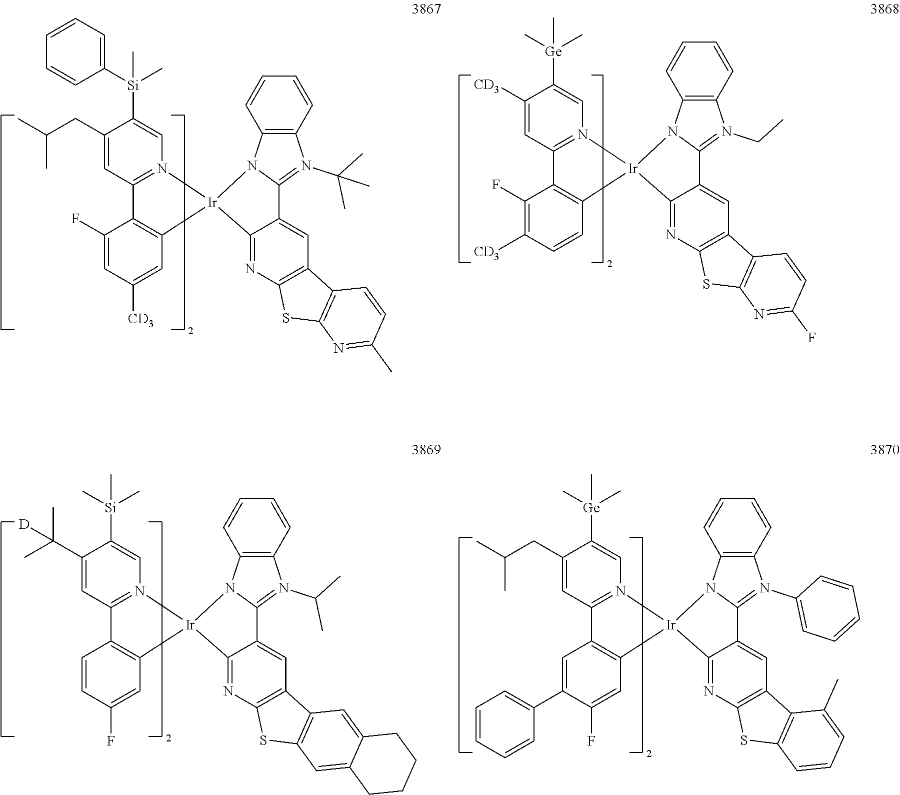

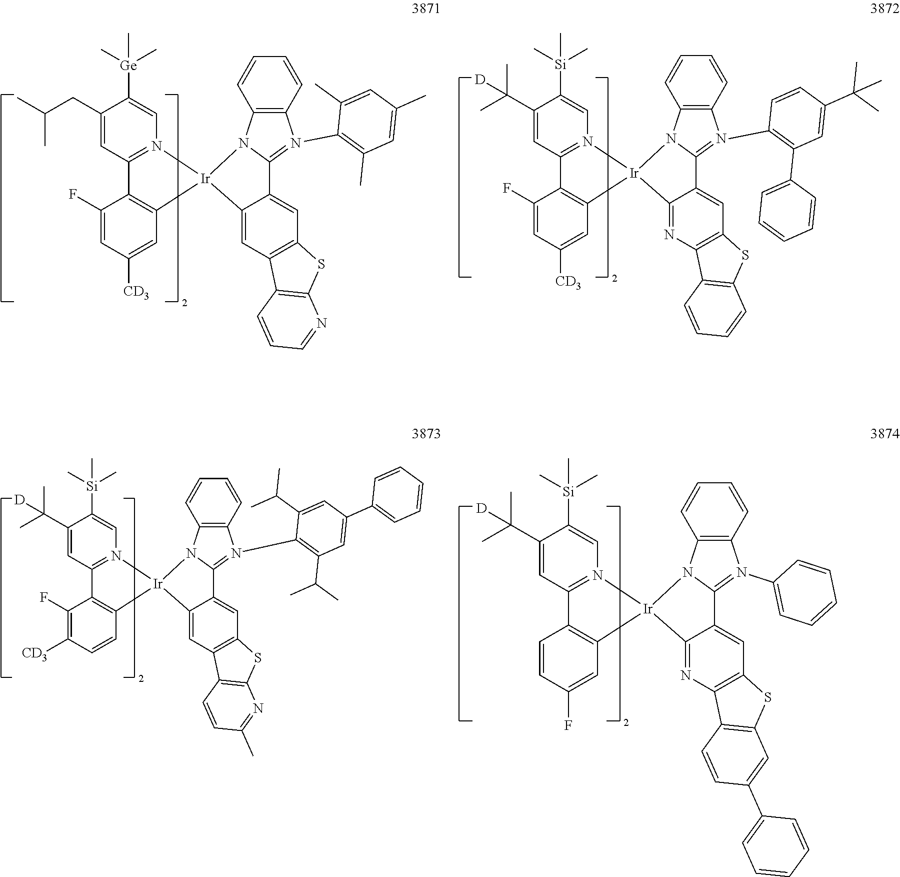

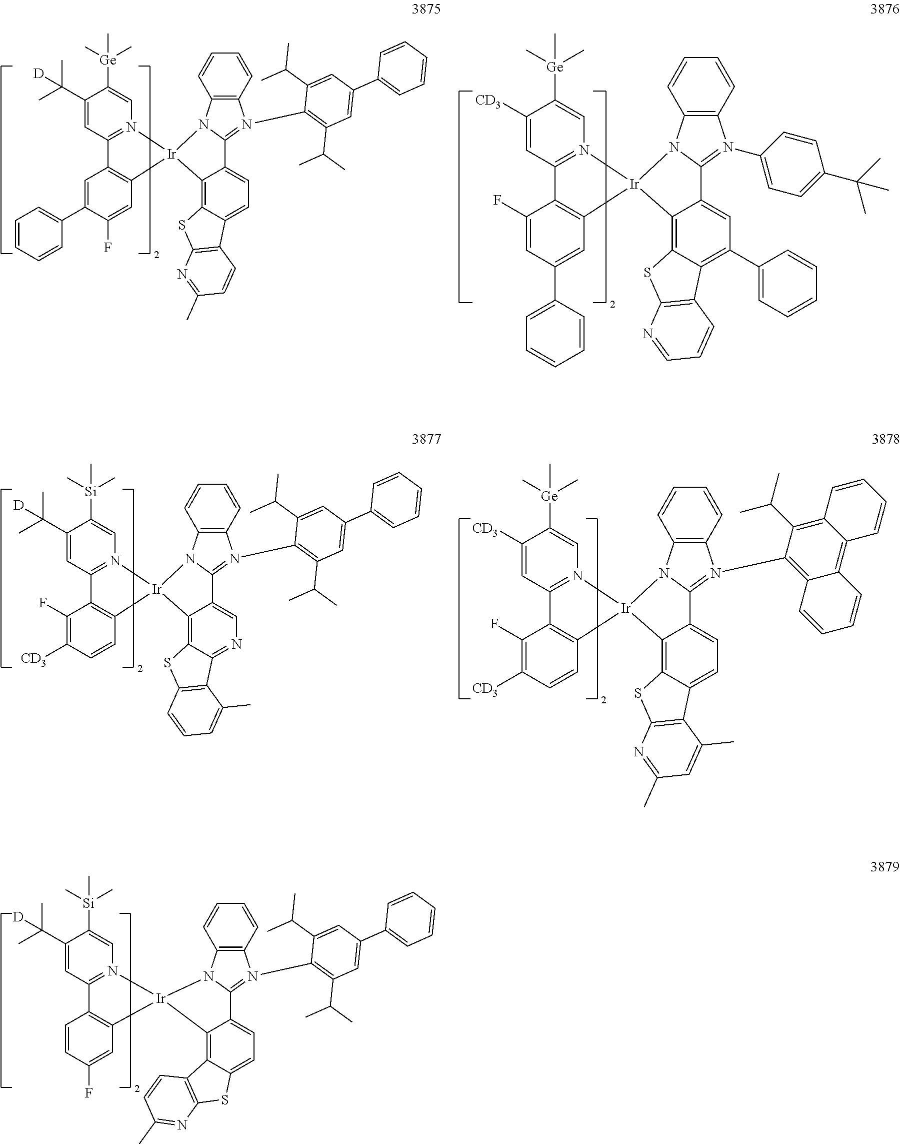

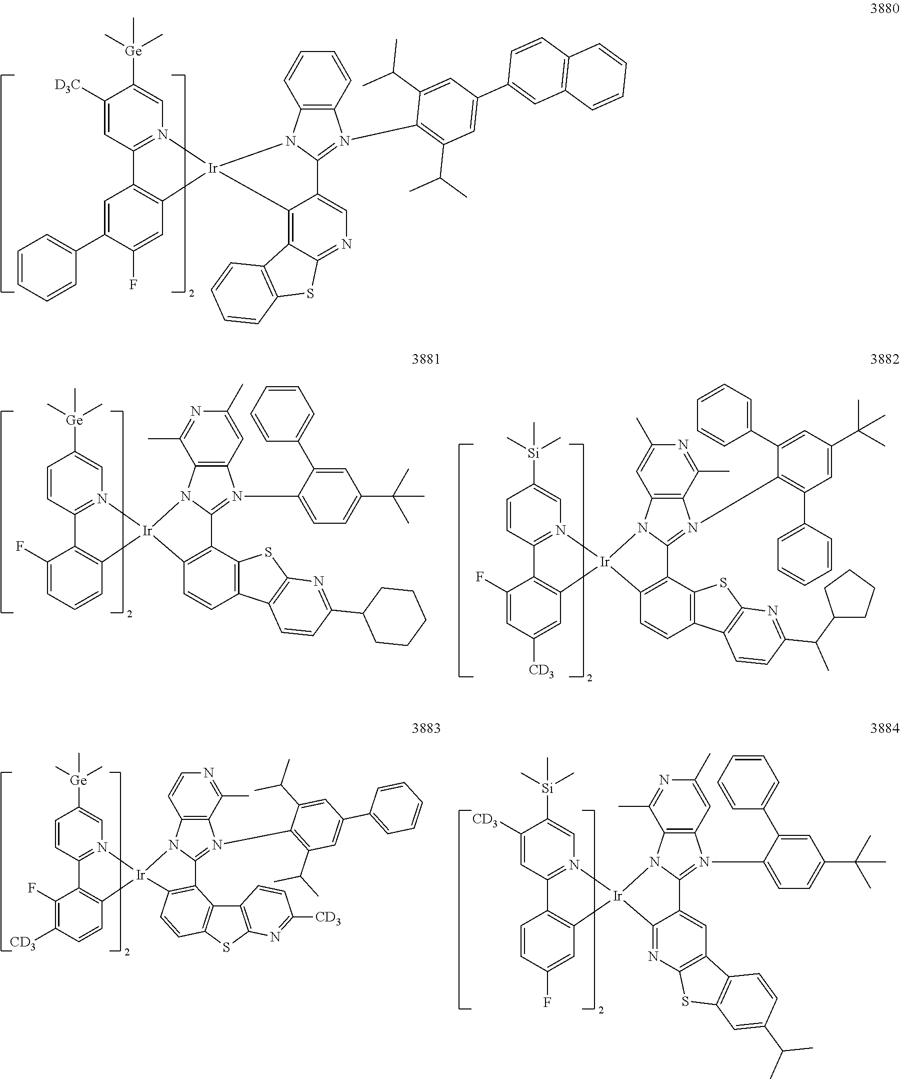

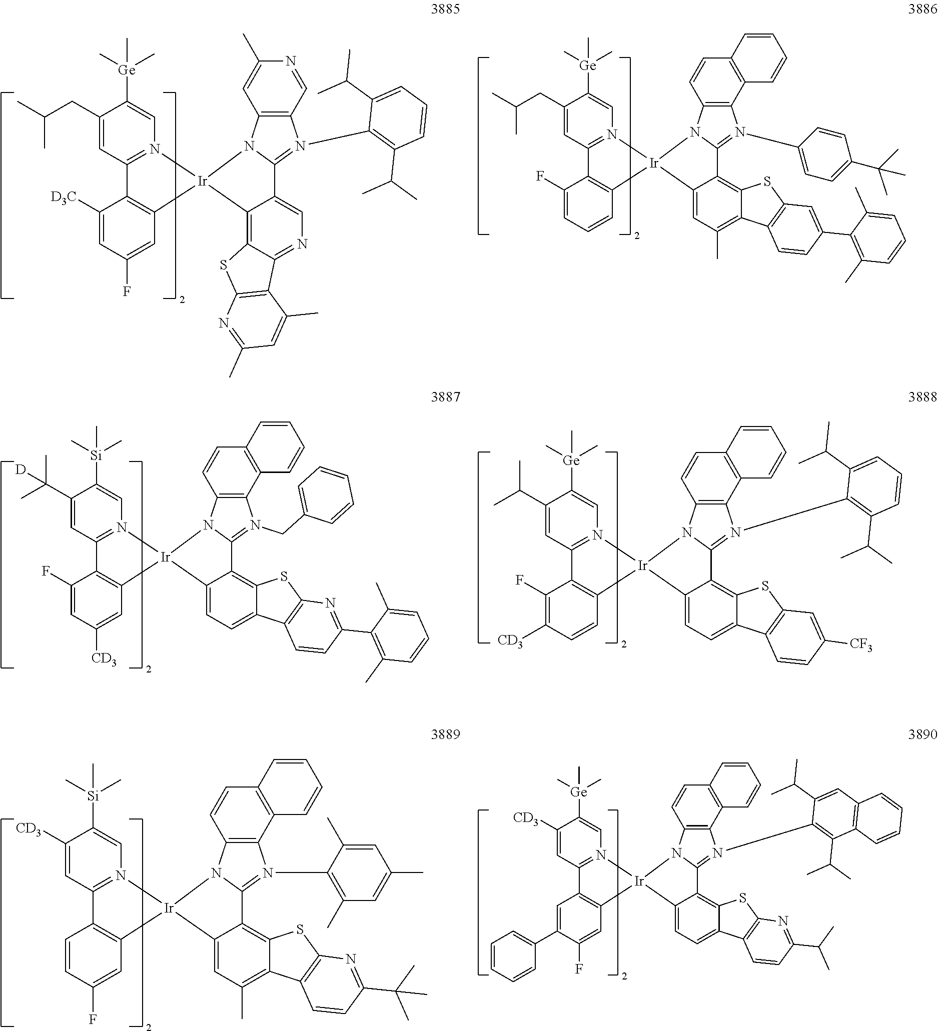

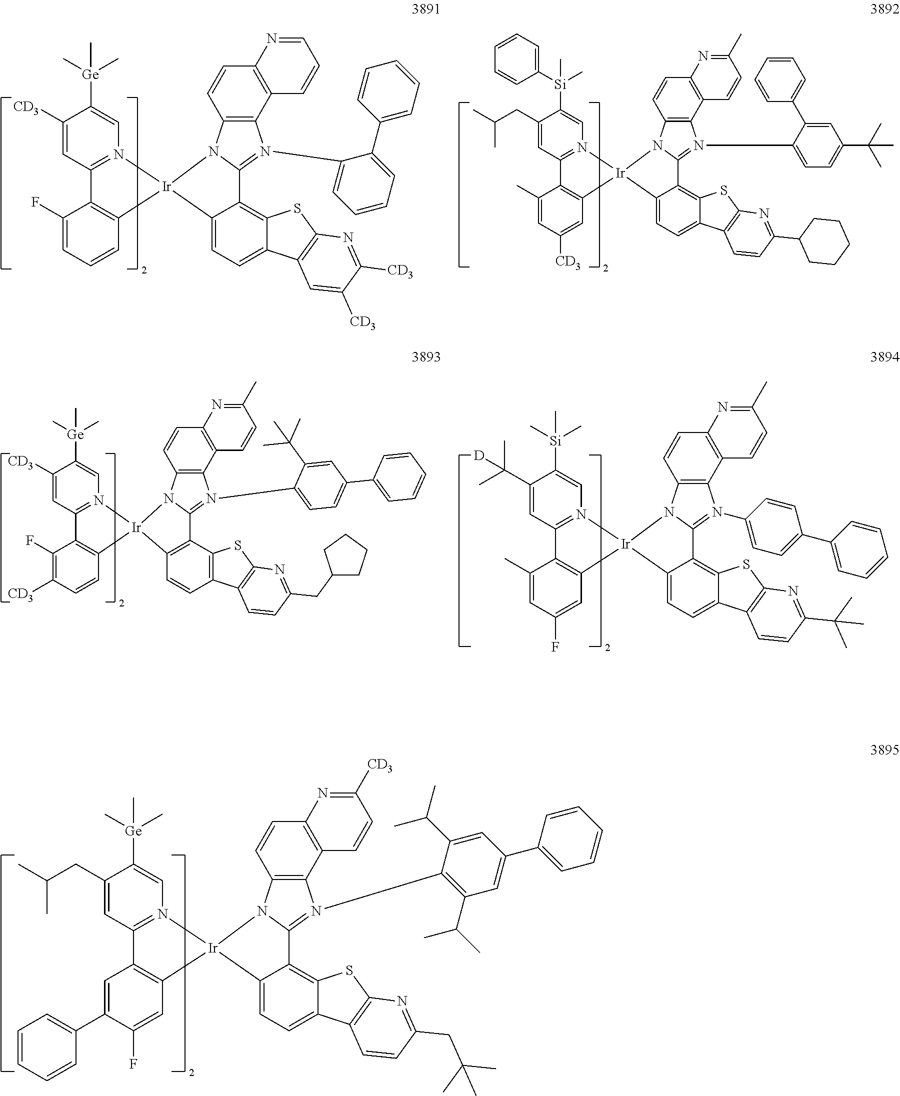

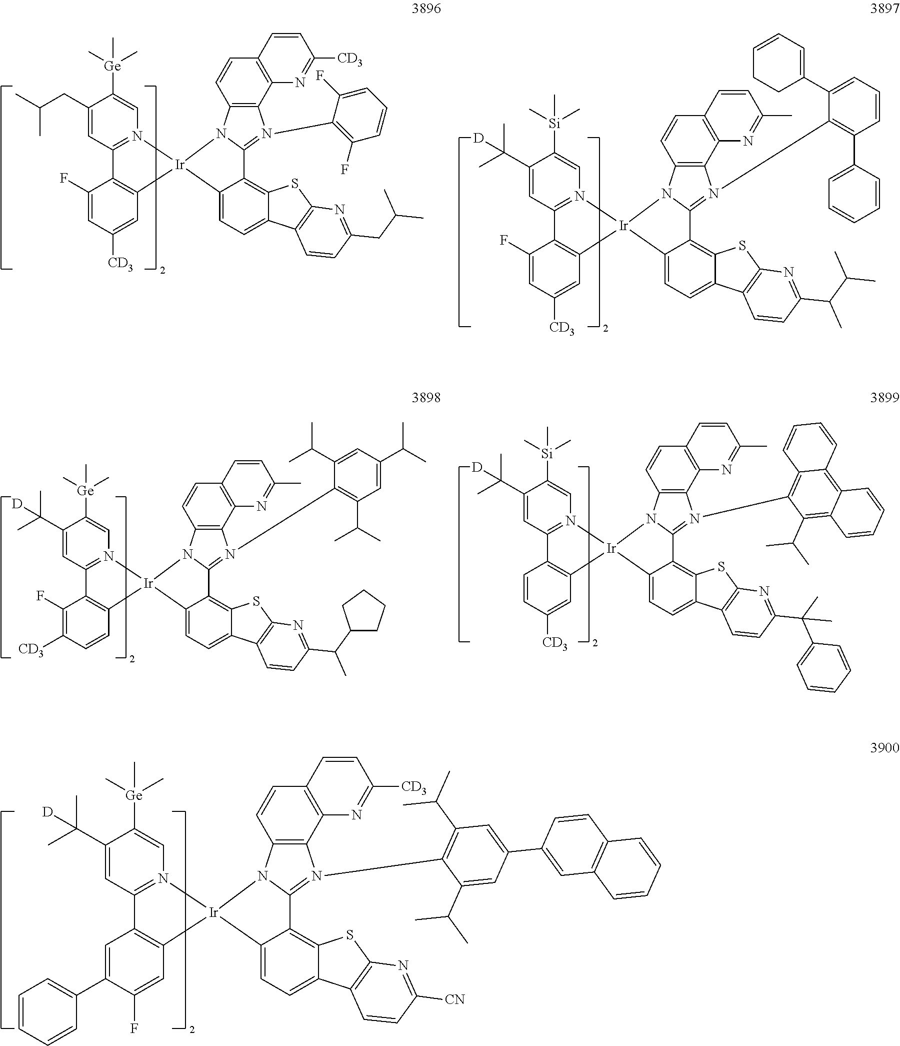

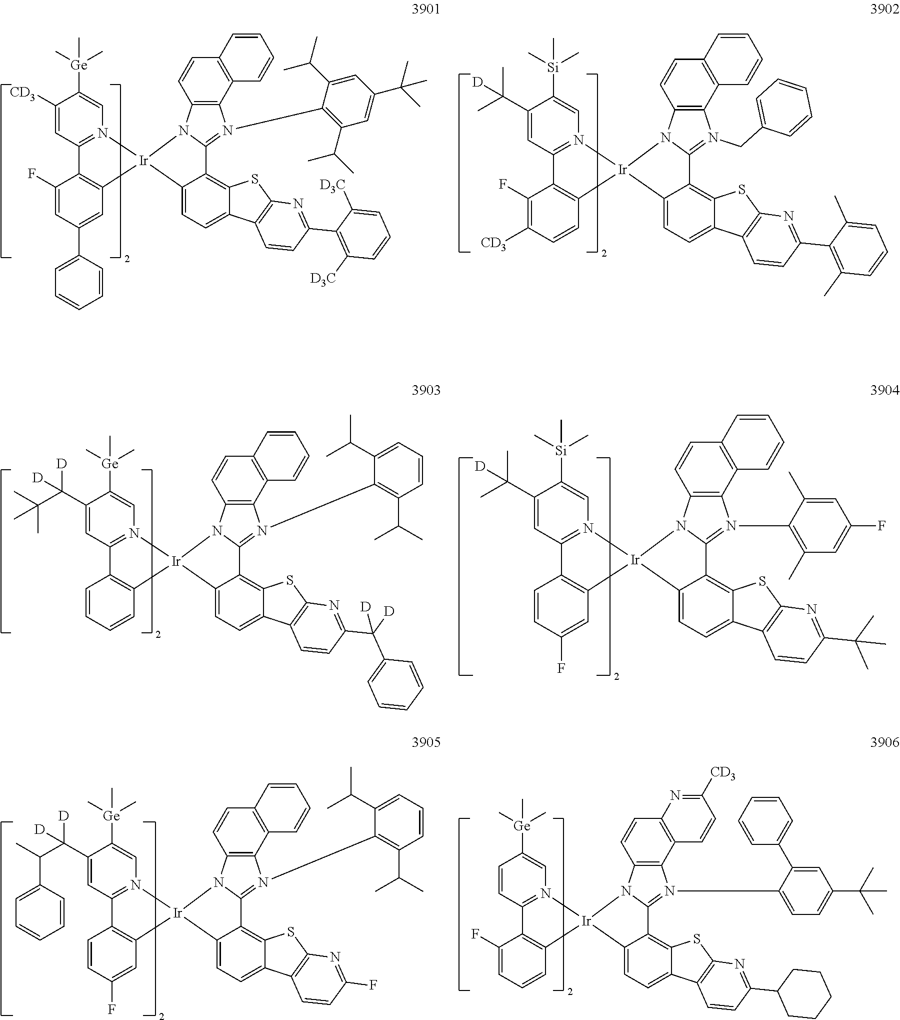

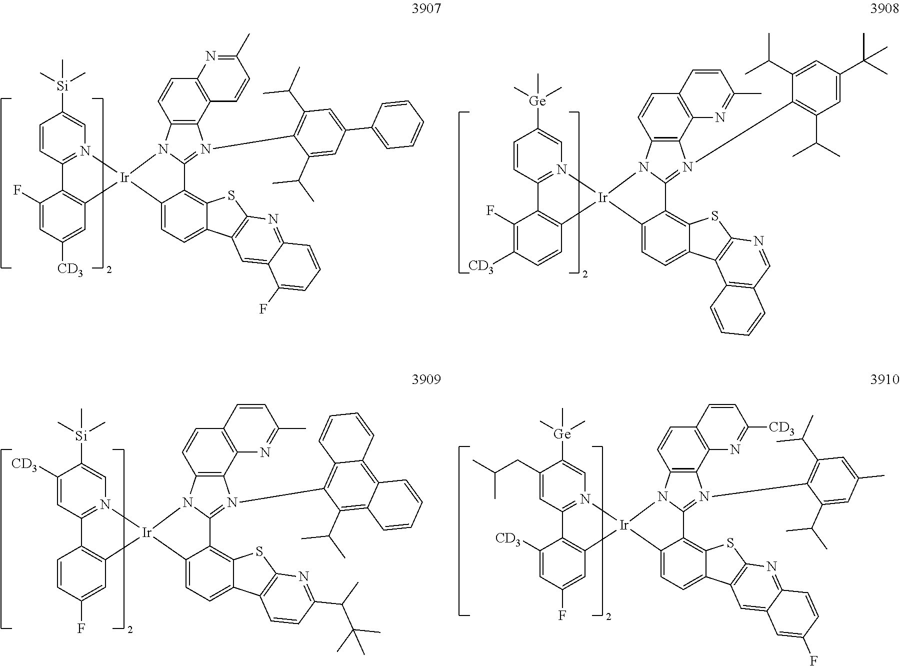

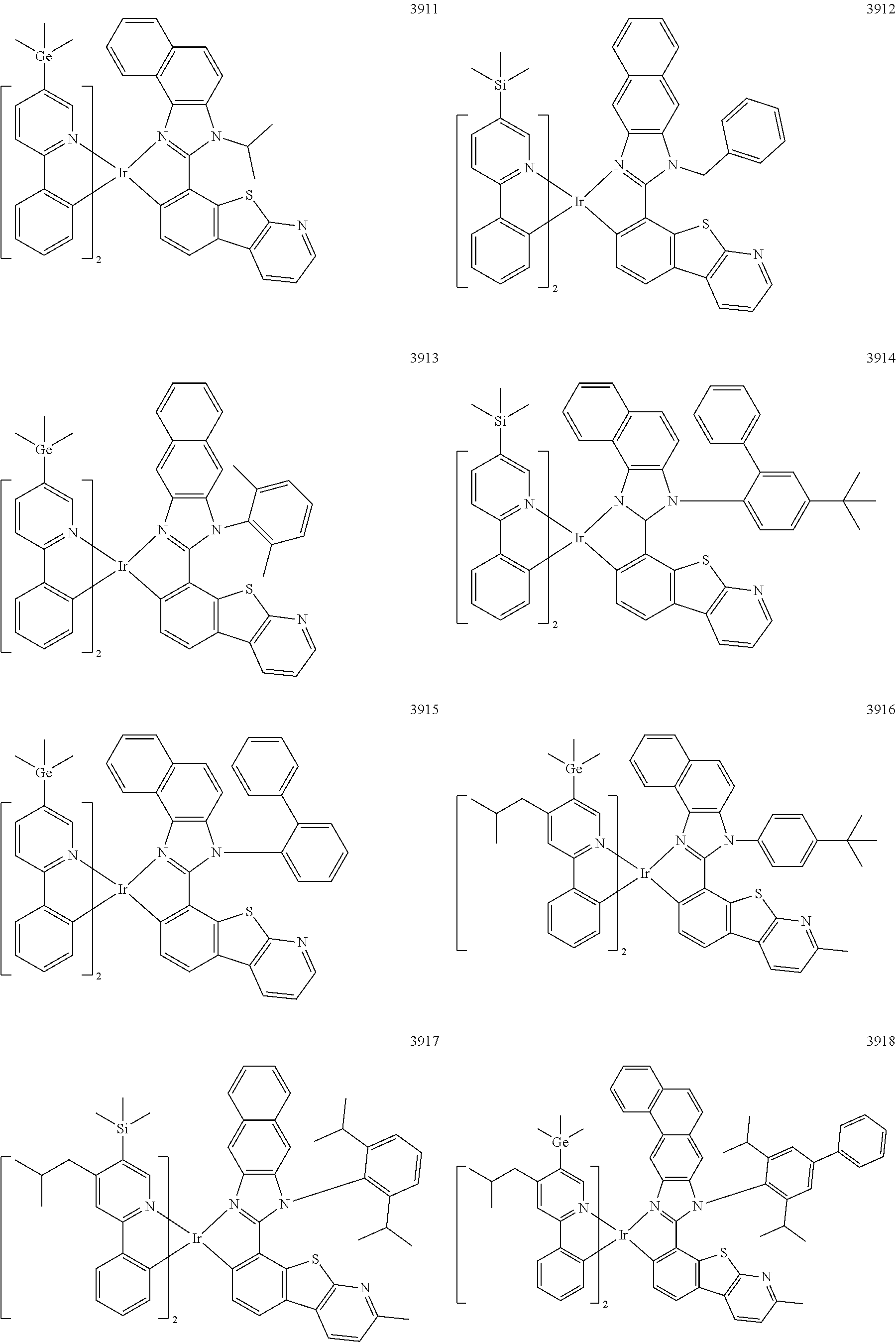

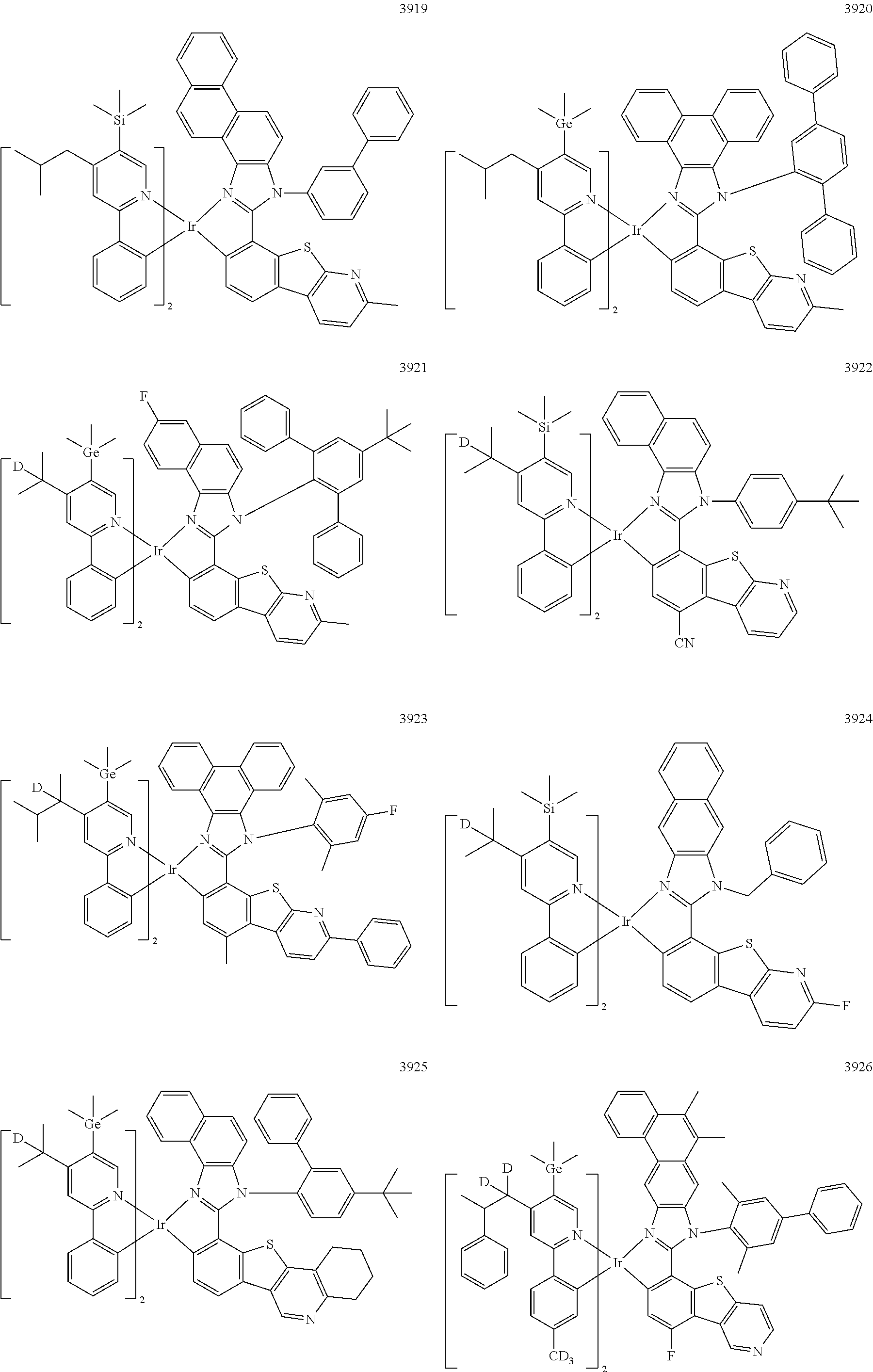

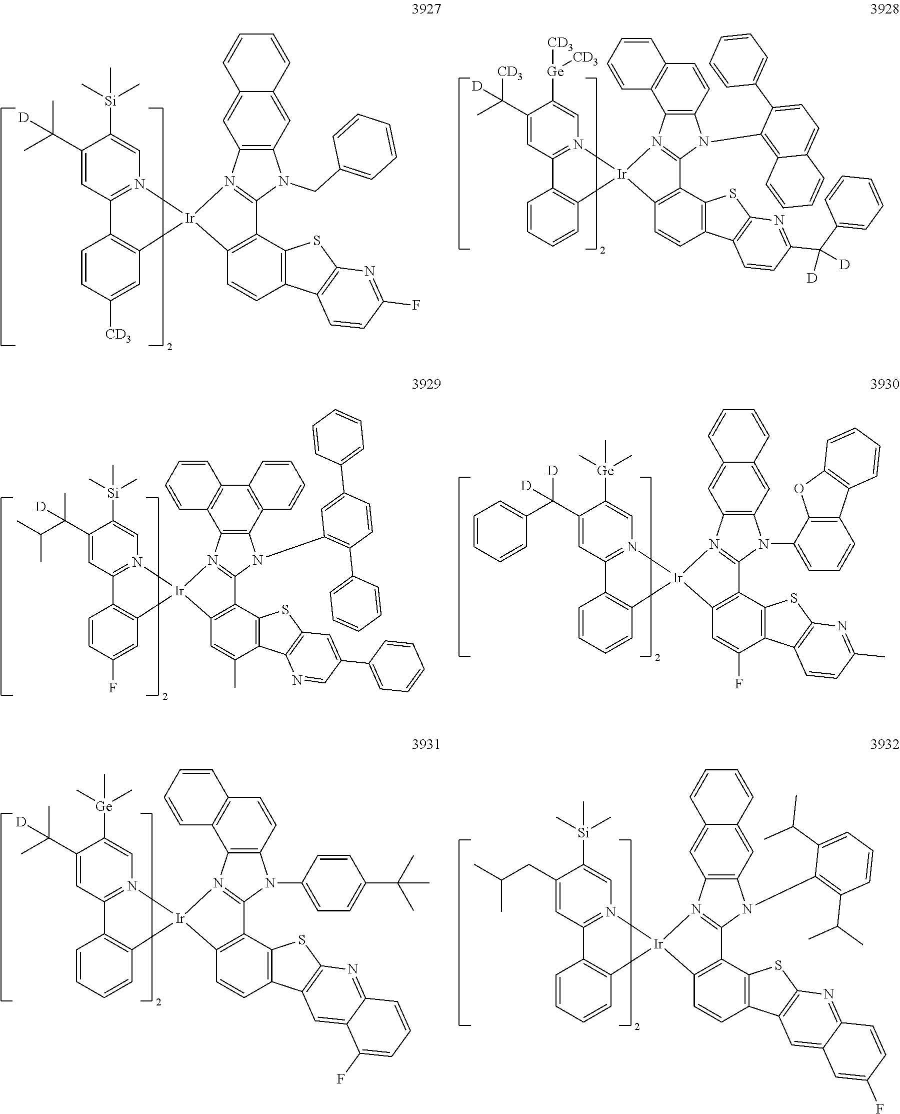

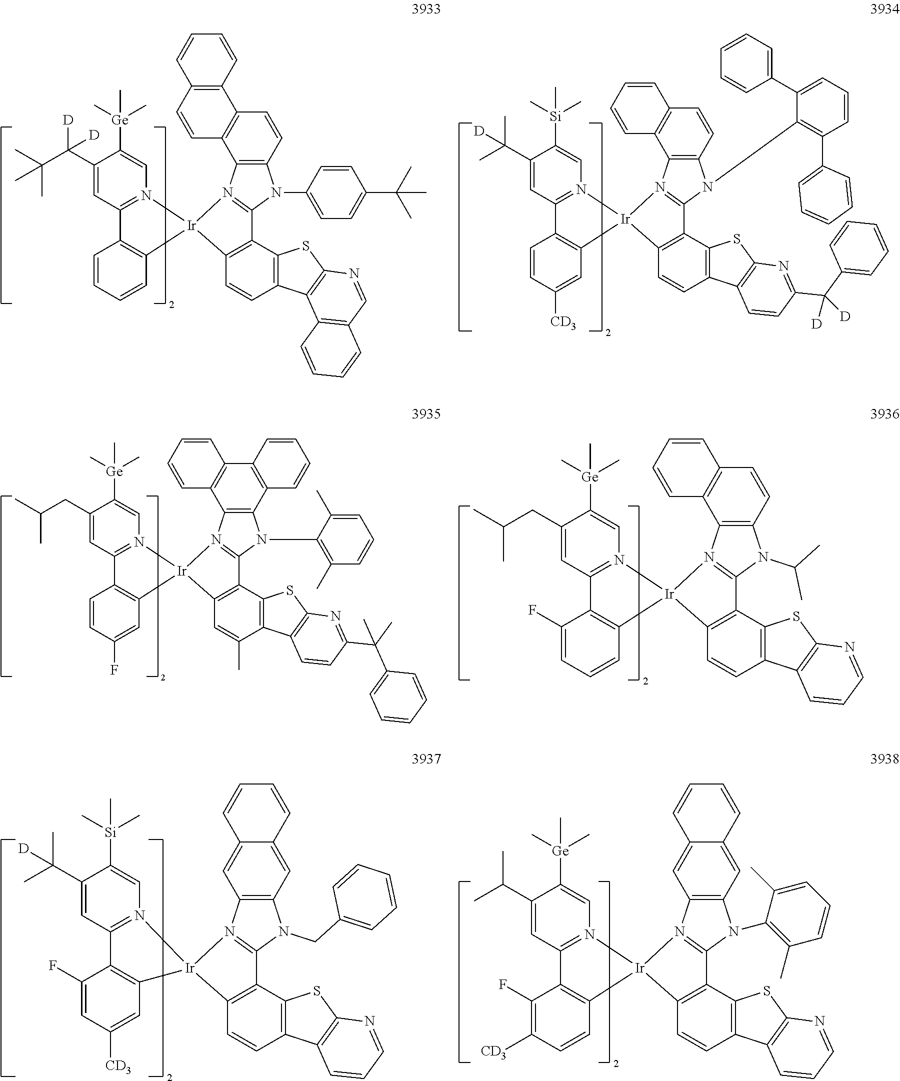

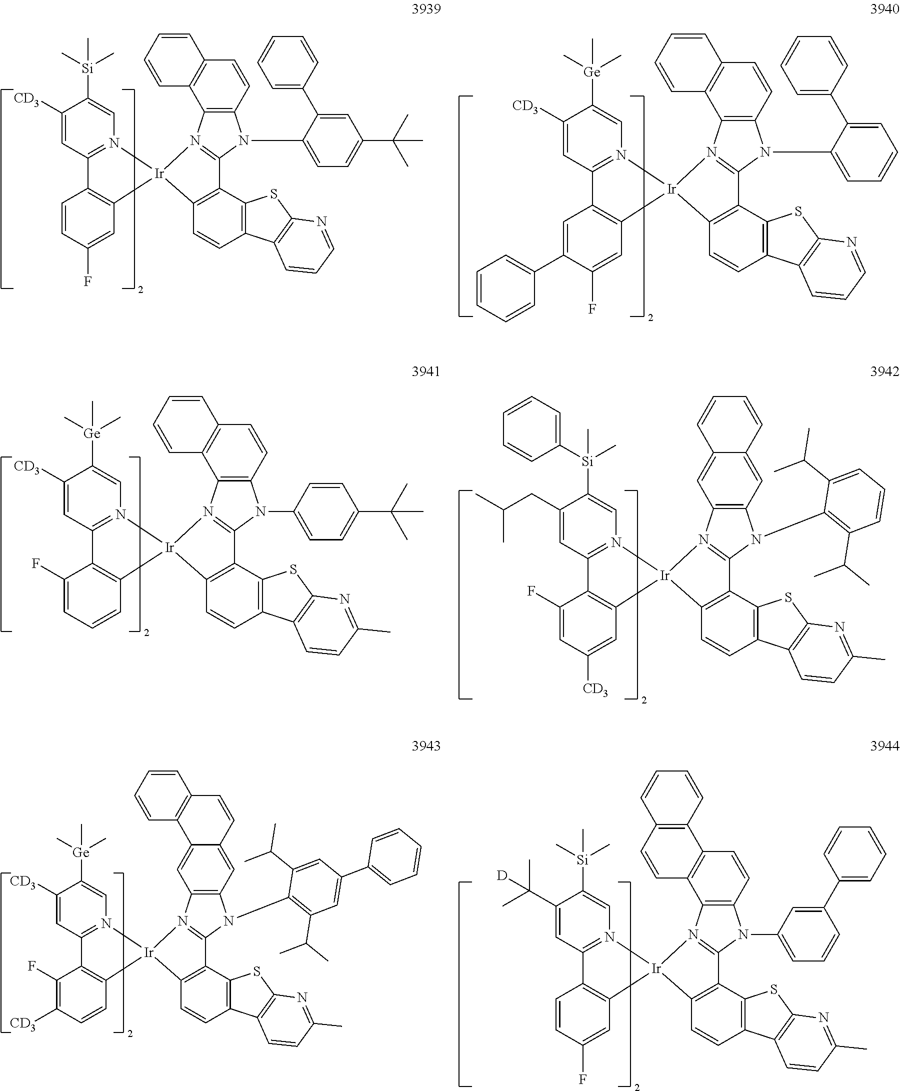

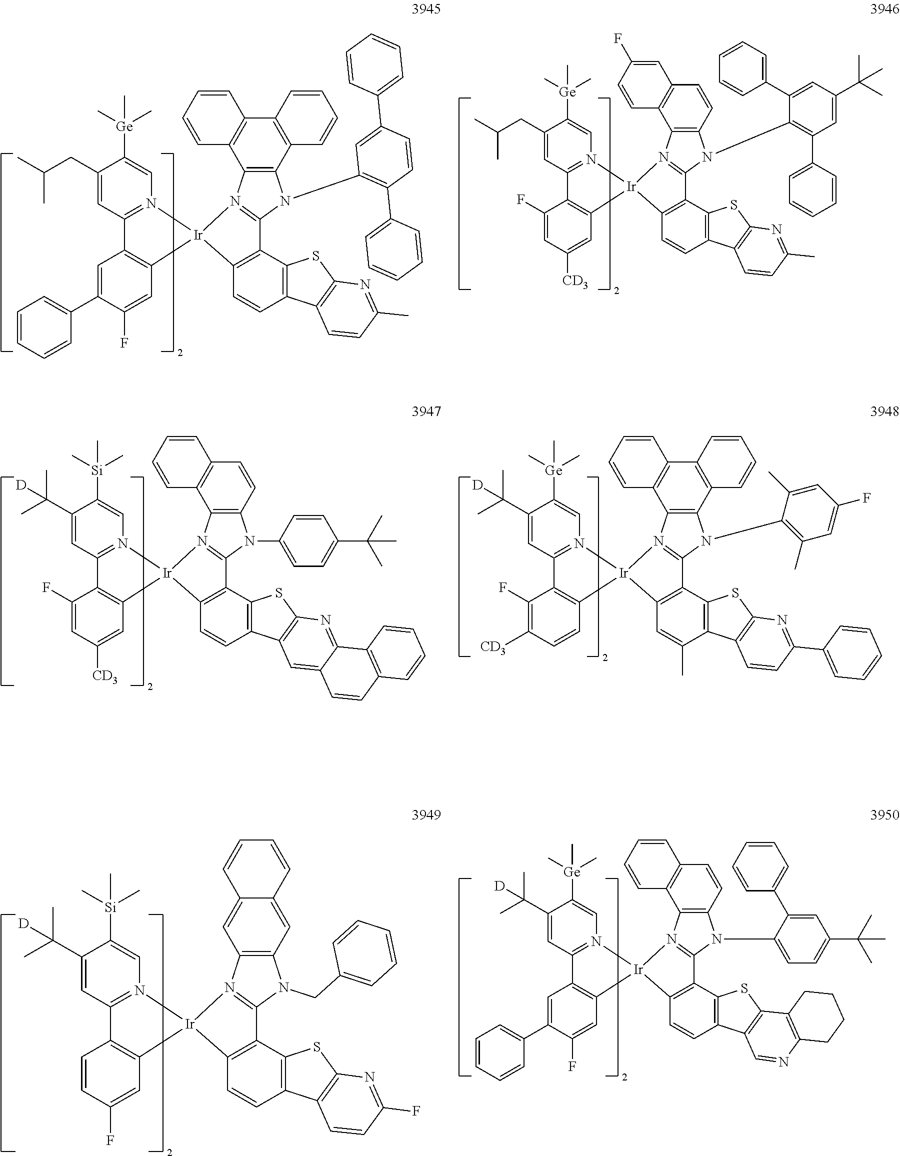

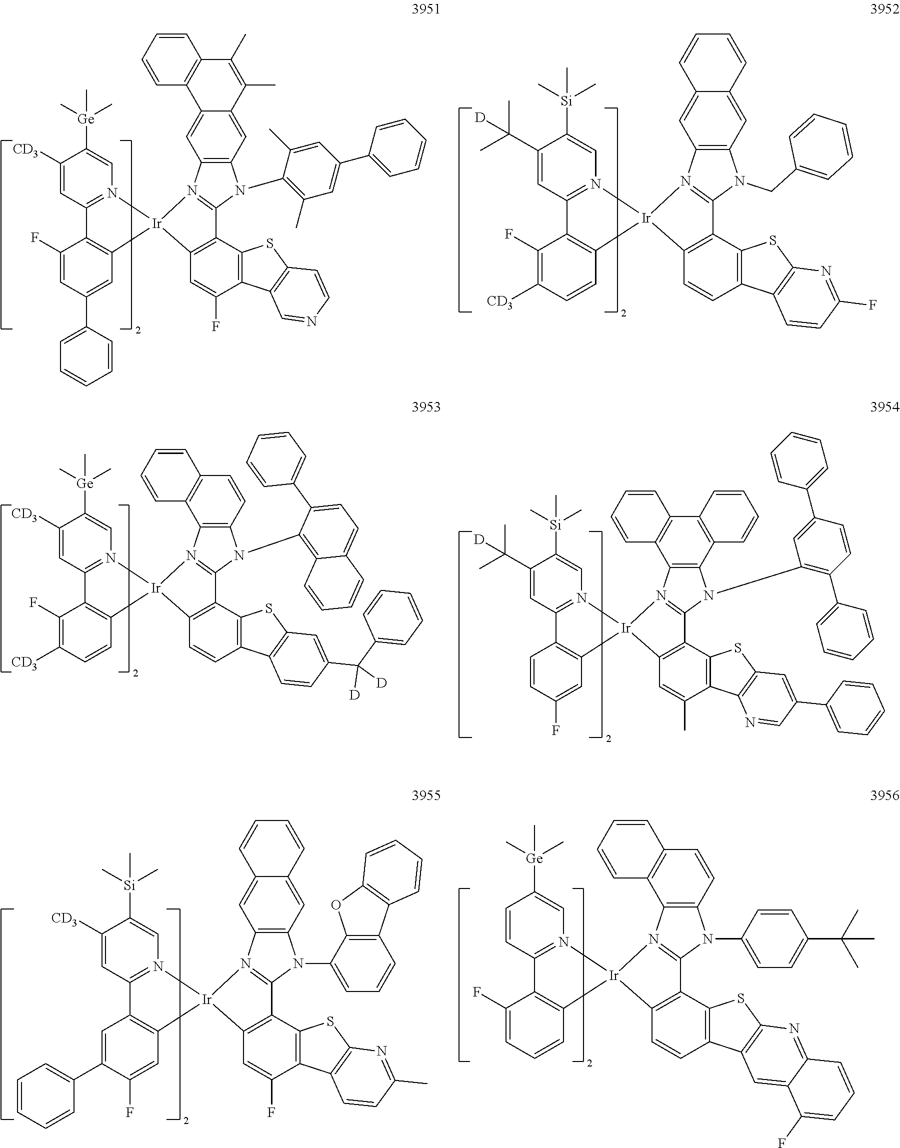

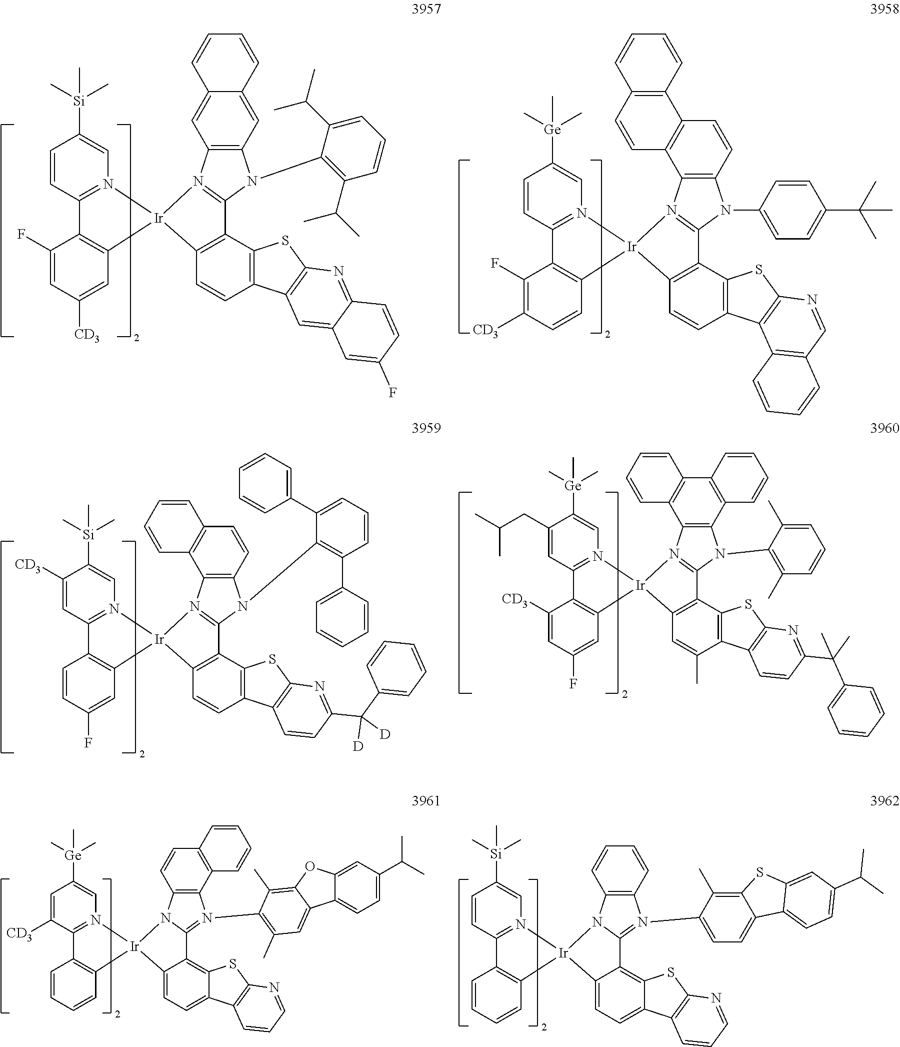

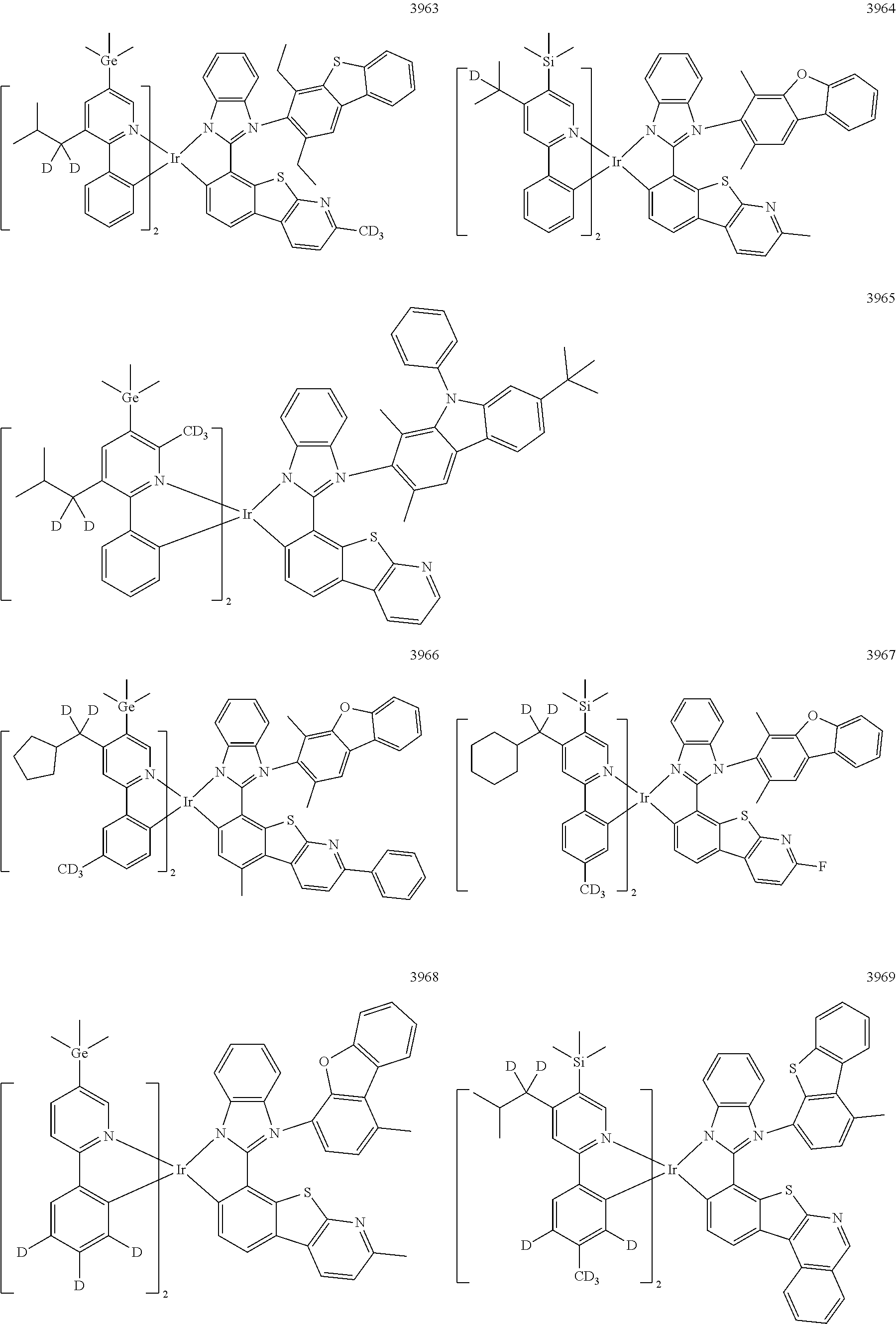

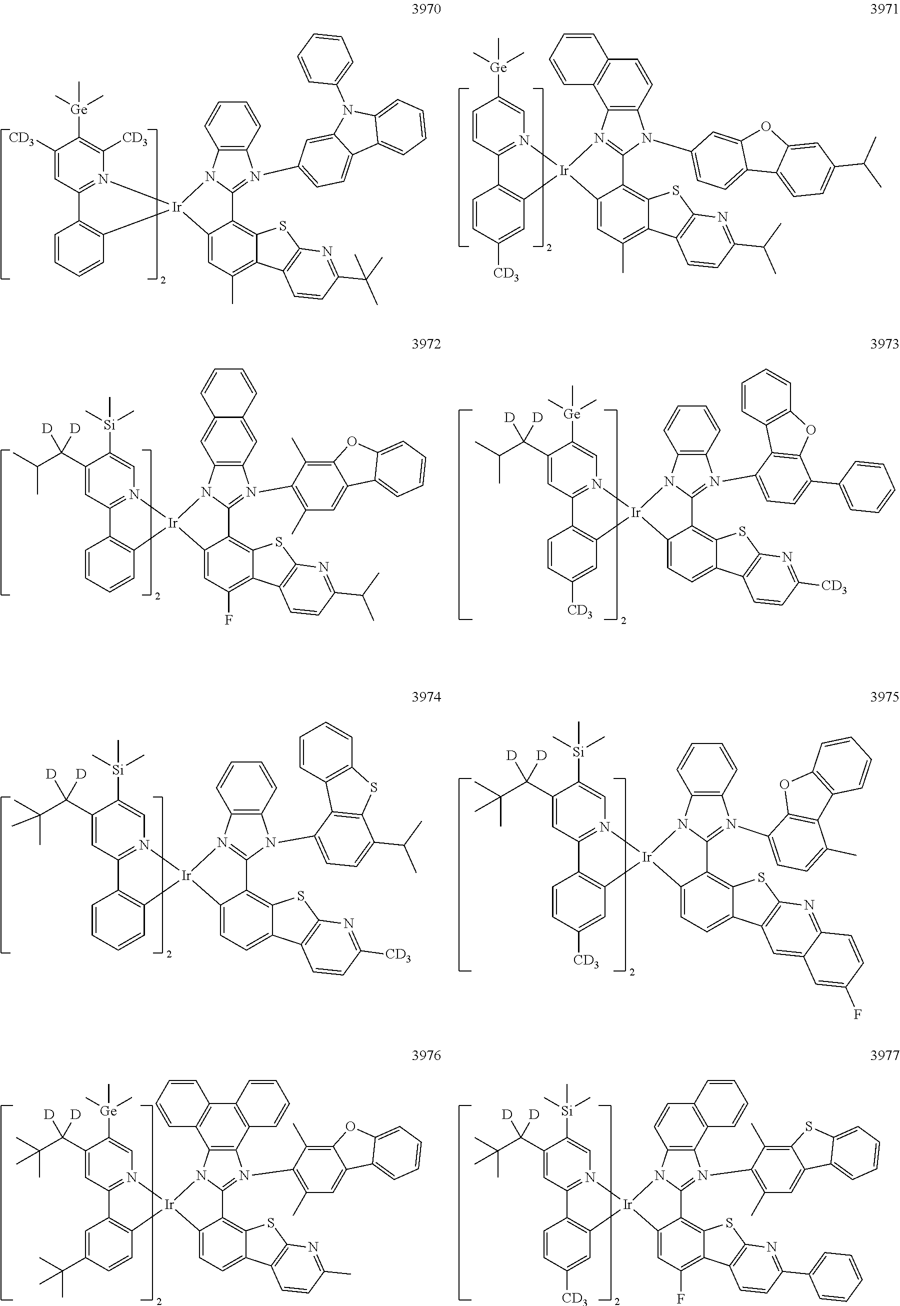

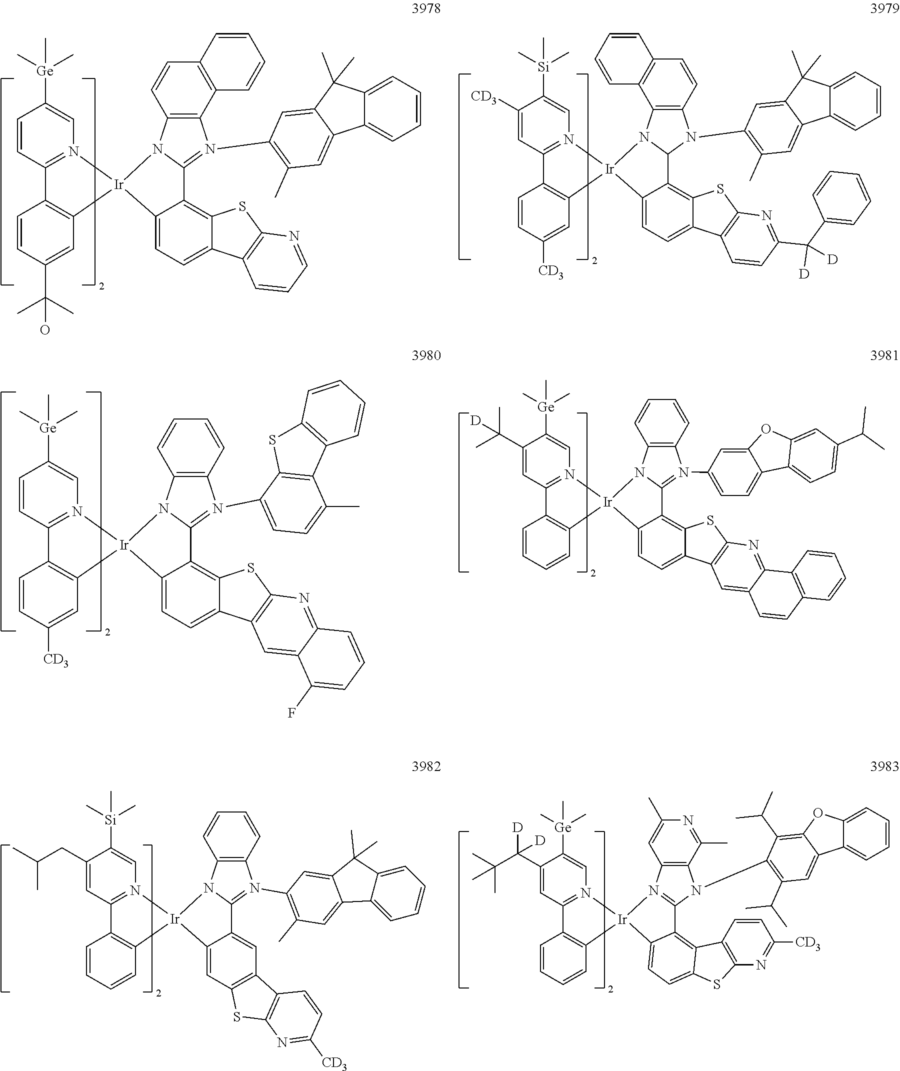

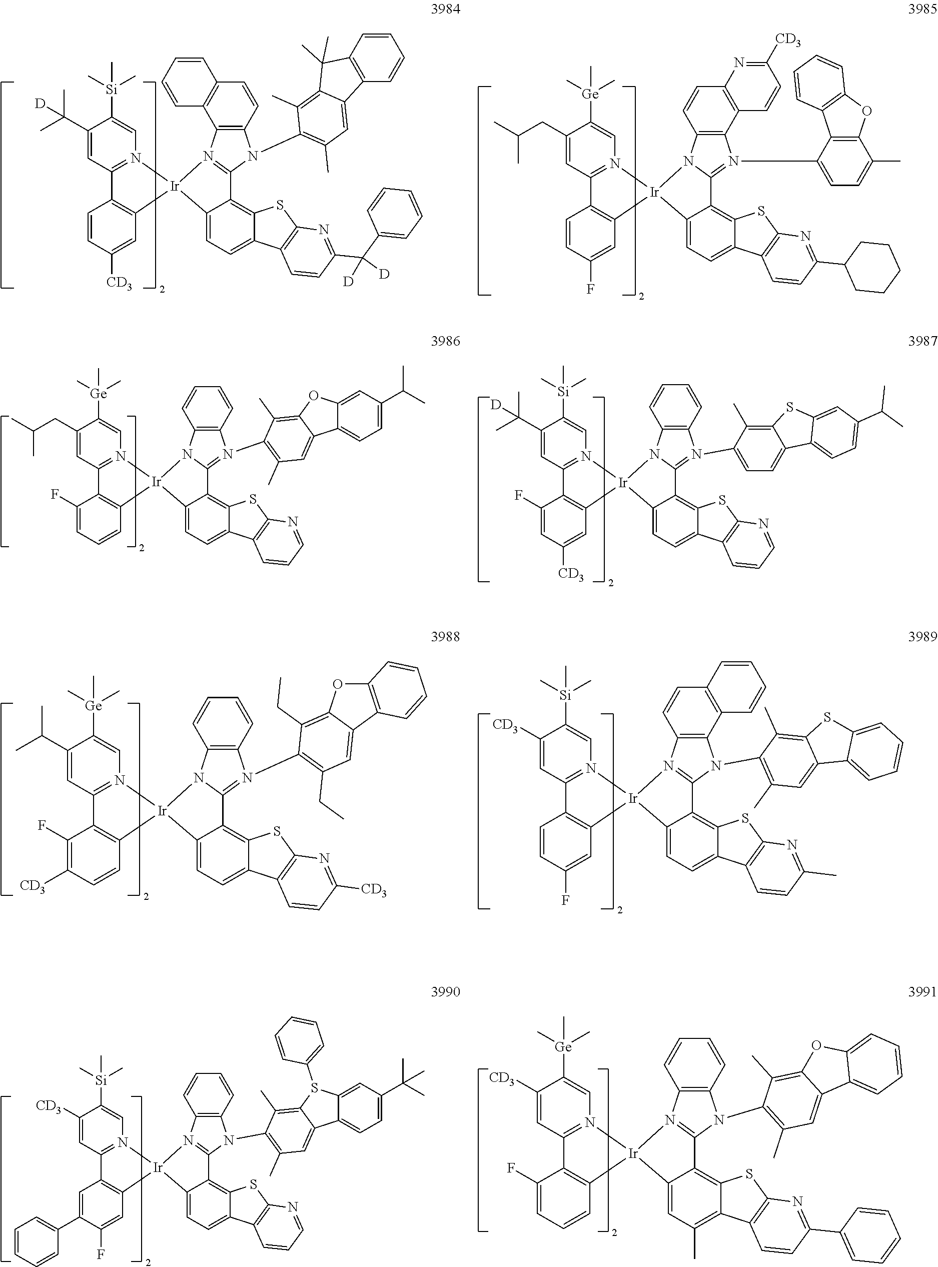

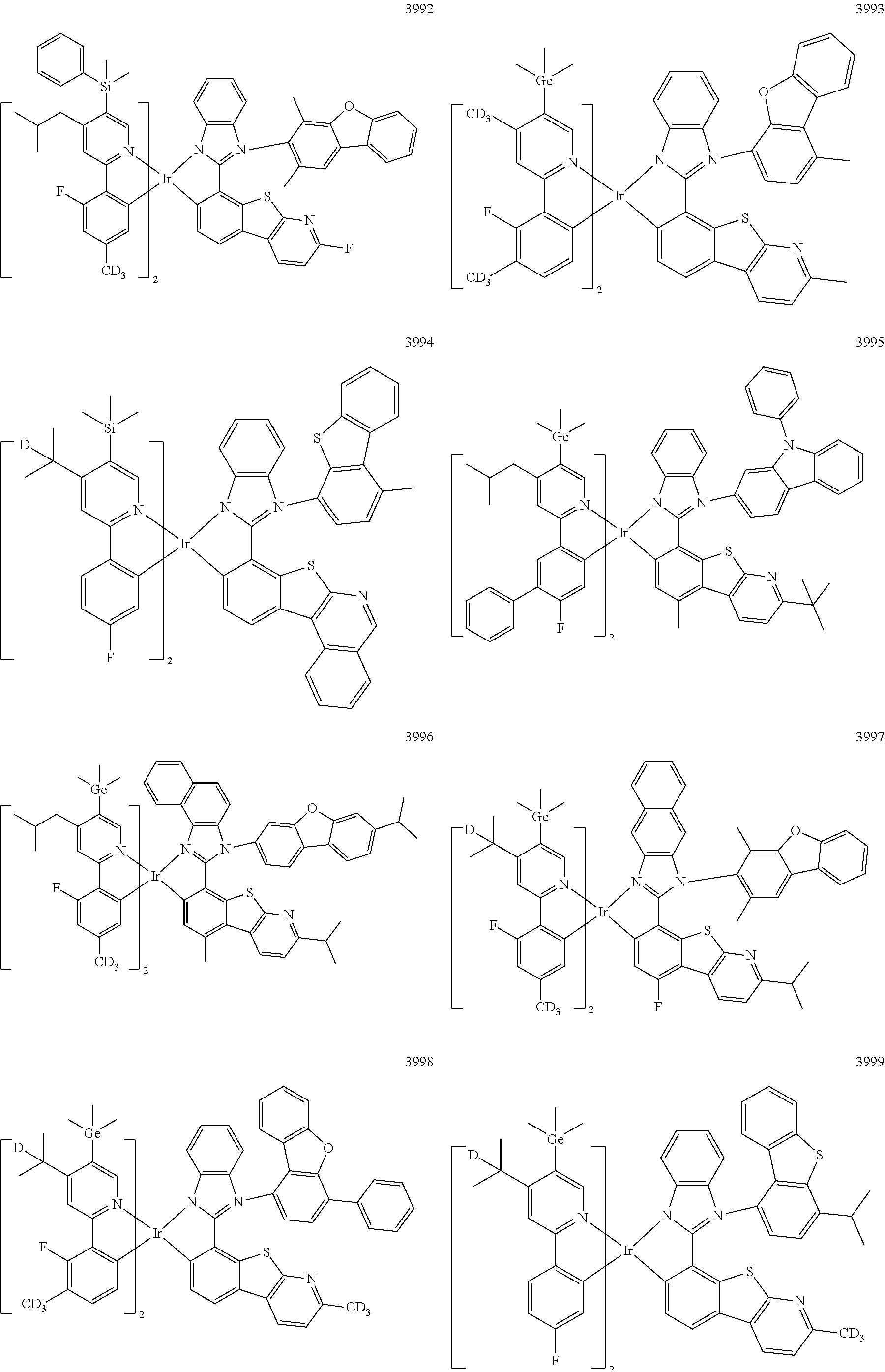

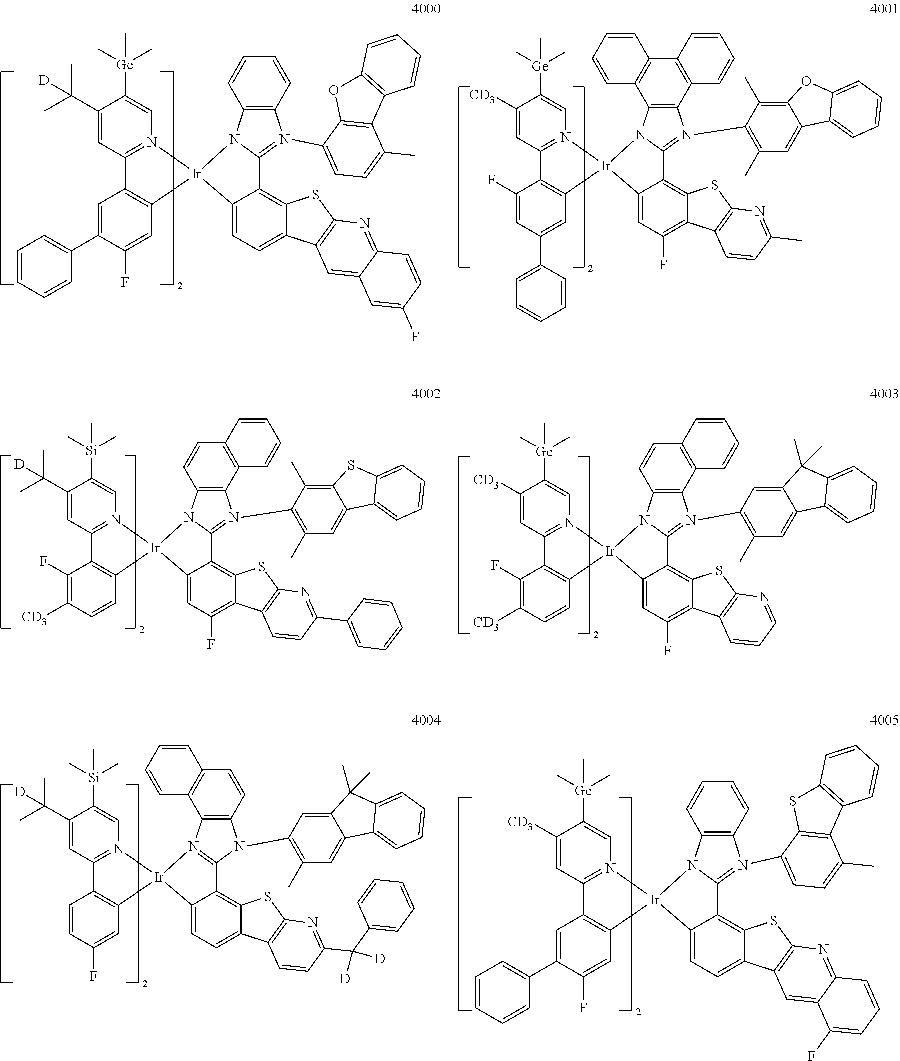

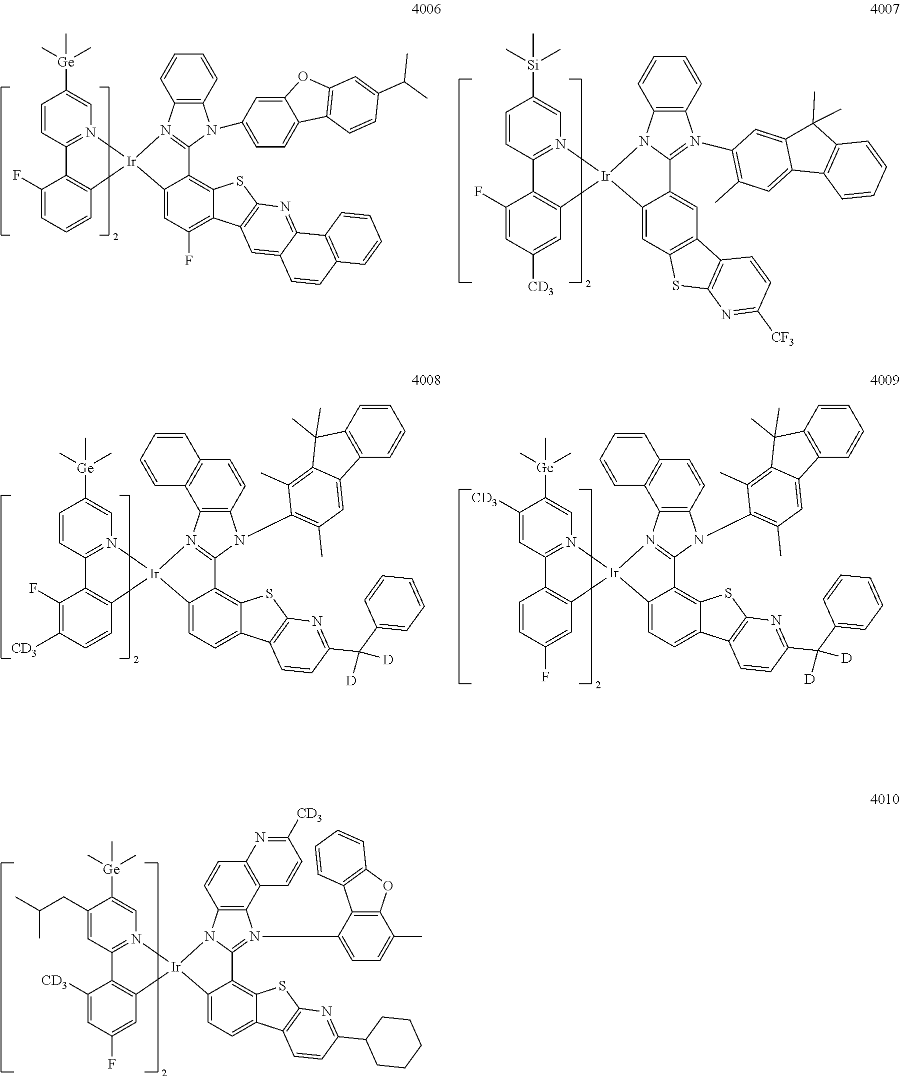

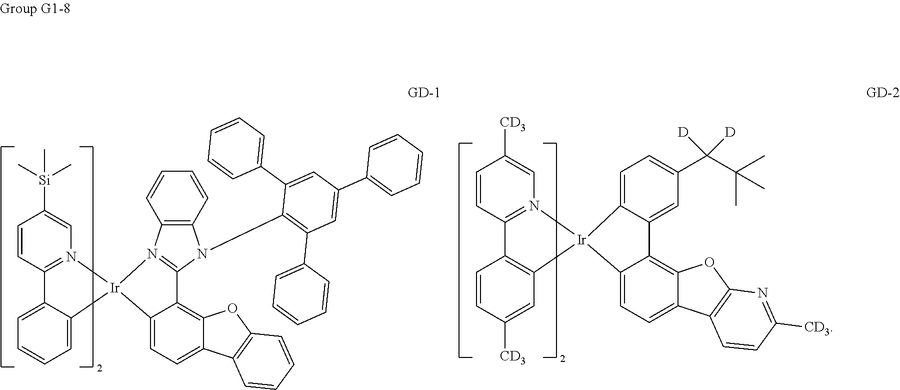

In one or more embodiments, the first compound and the second compound may each independently be one of the compounds of Groups R₁-1 to R₁-8: Group R₁-1

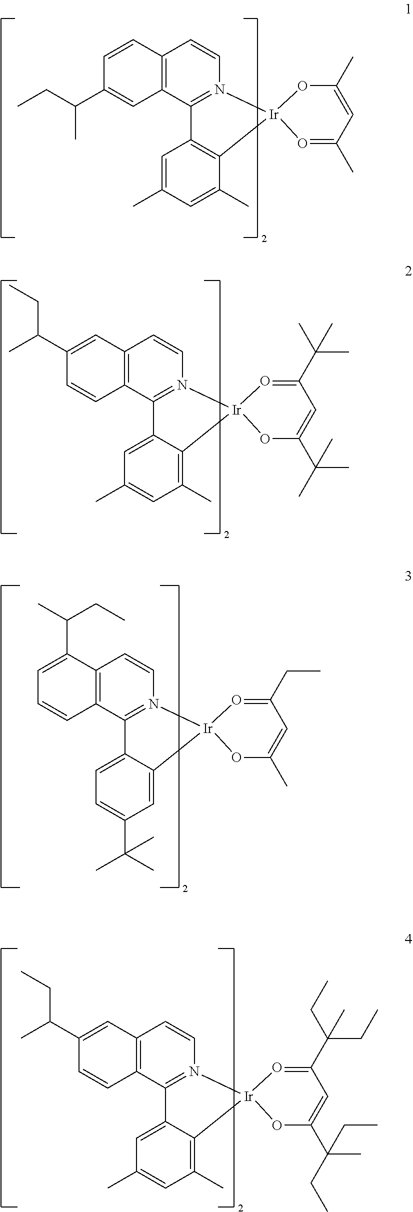

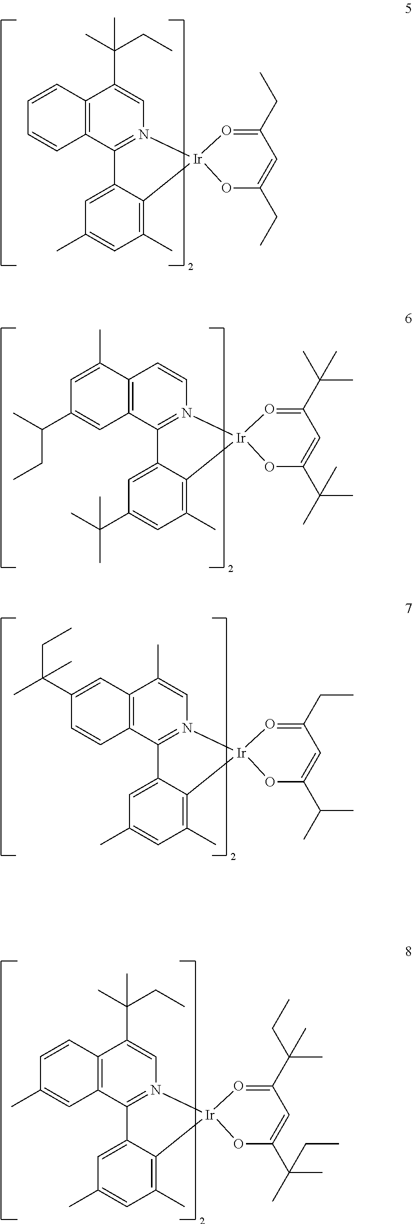

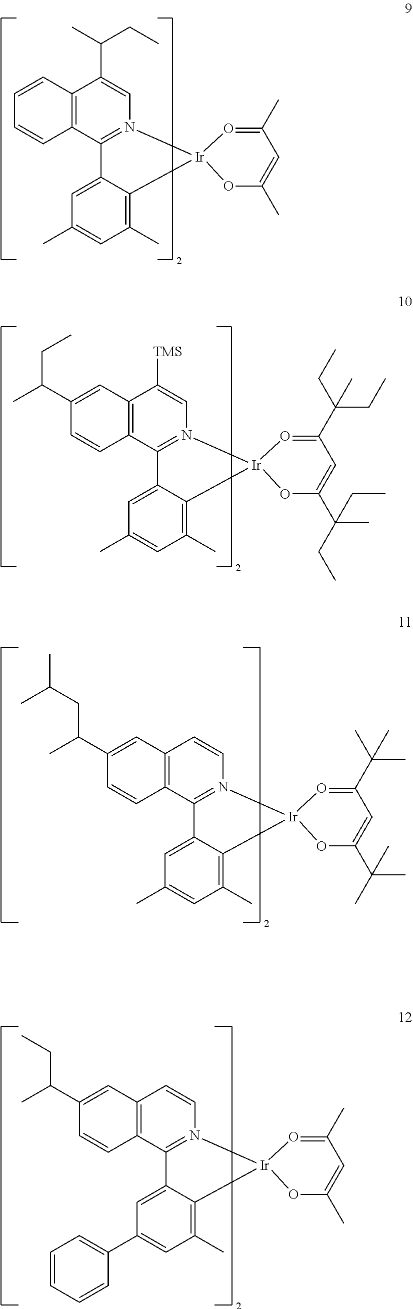

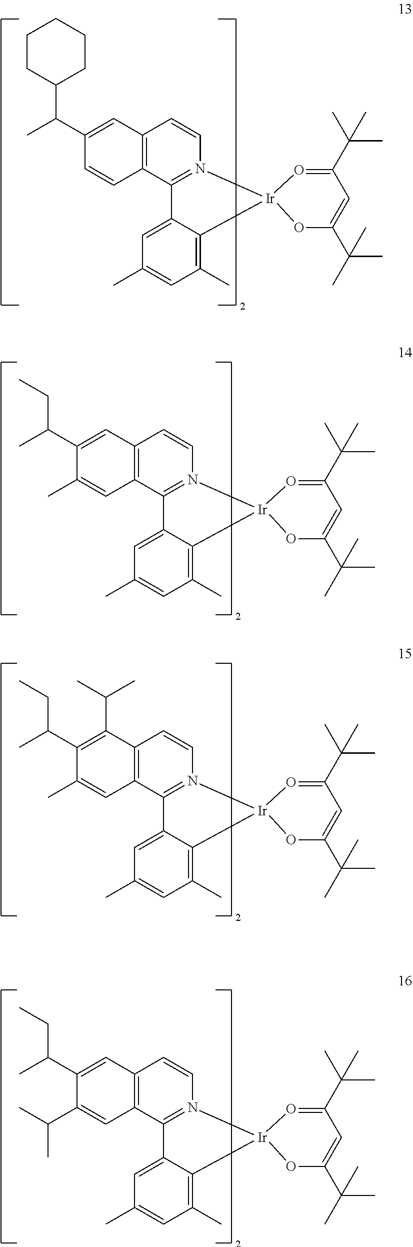

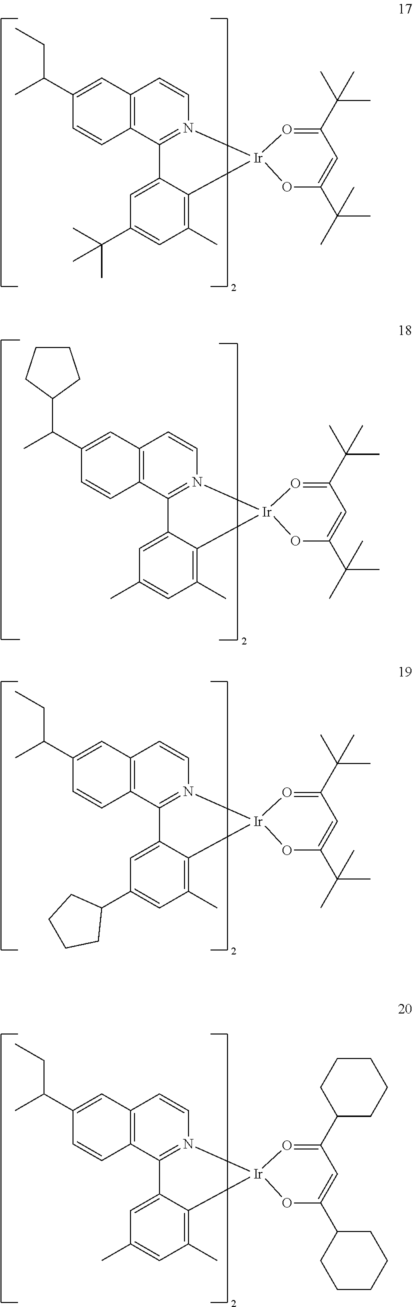

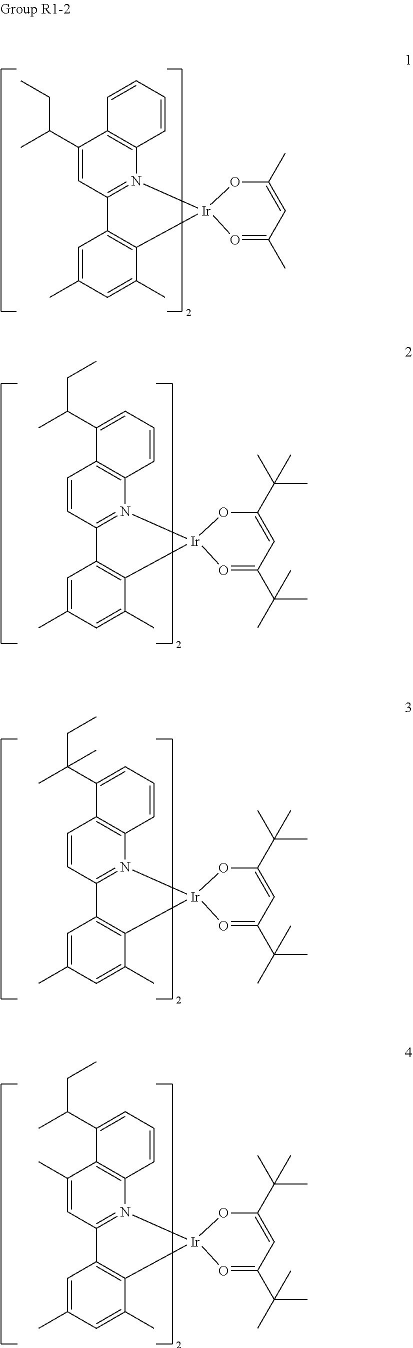

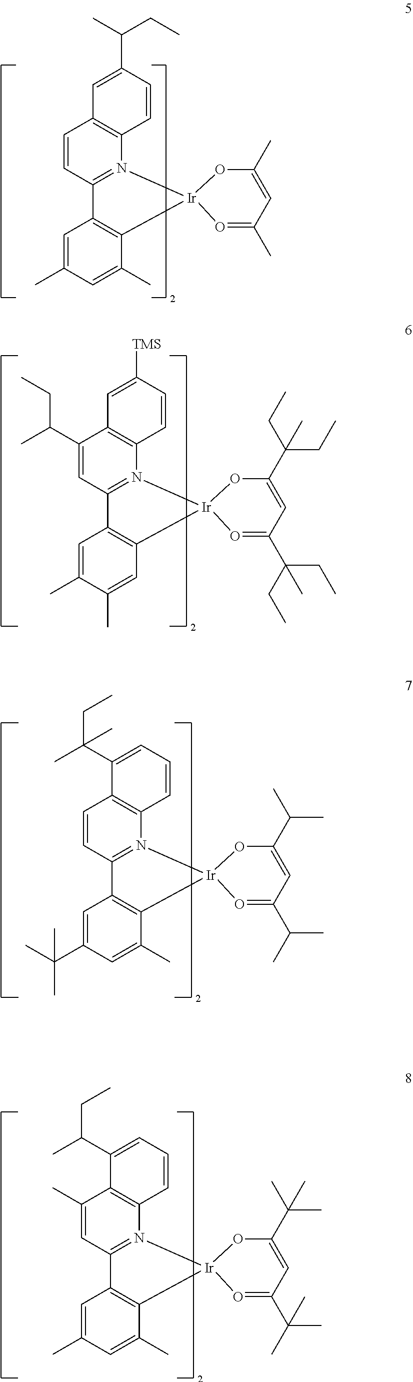

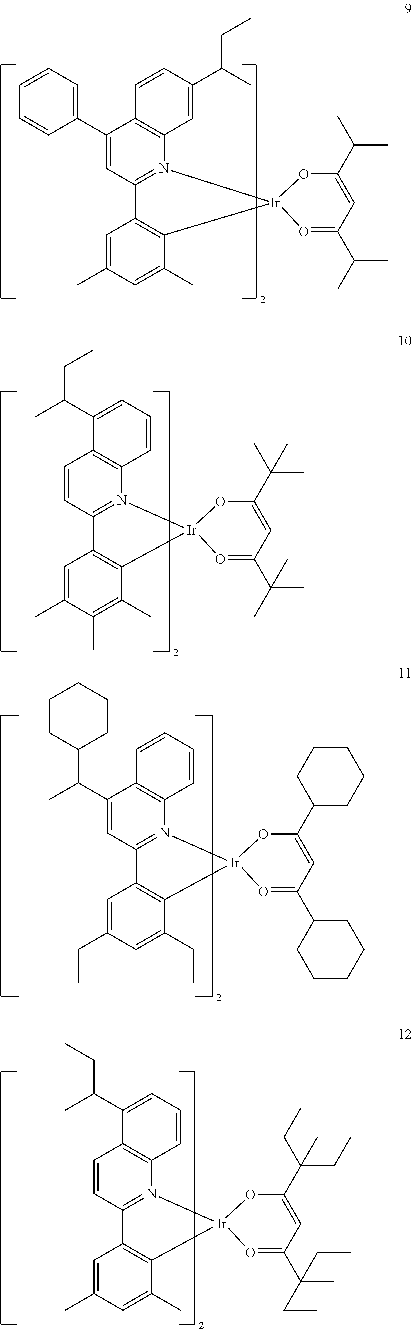

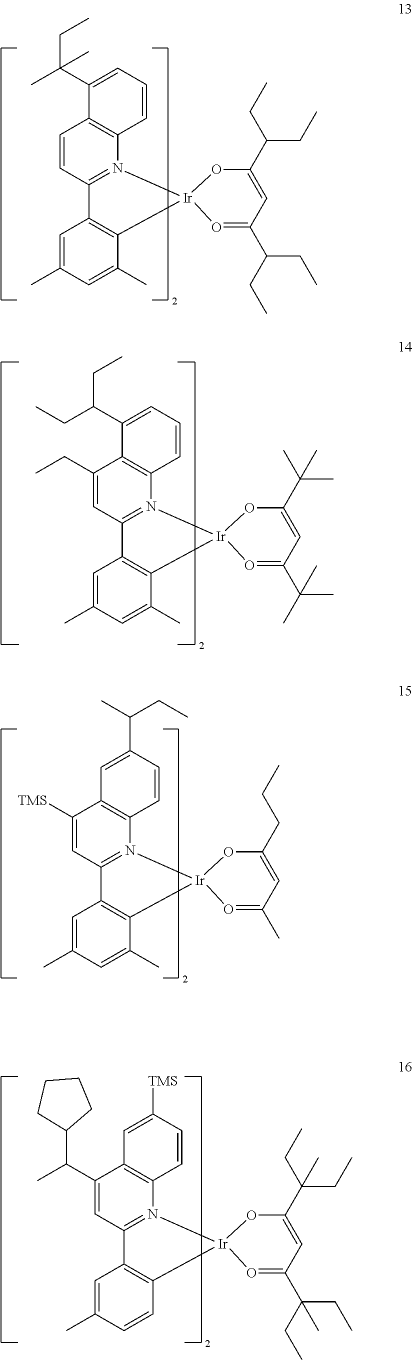

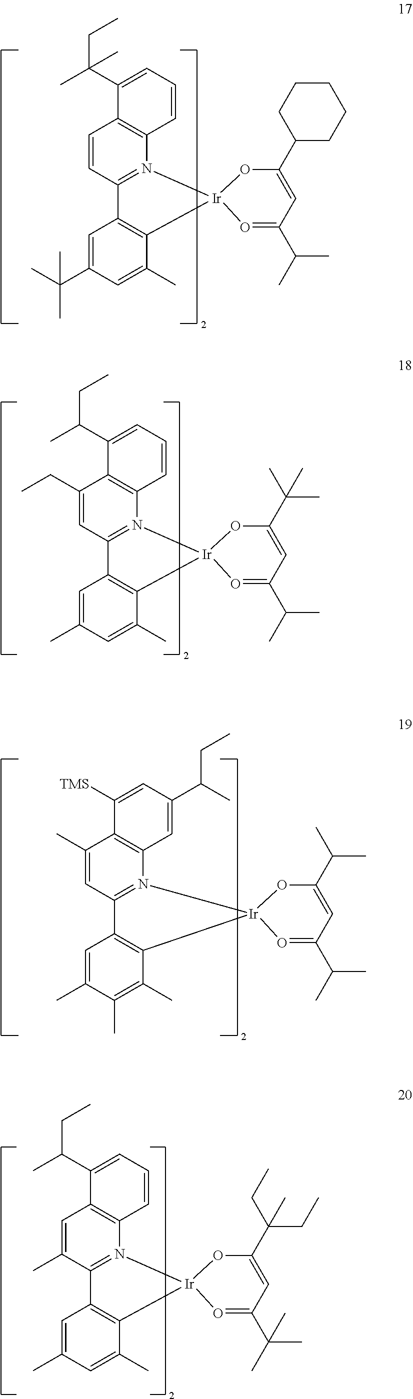

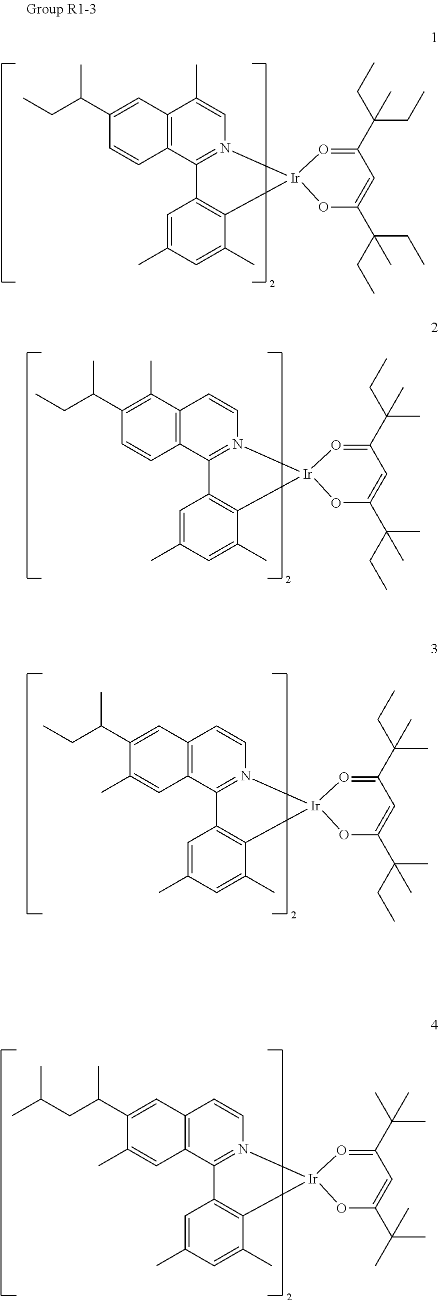

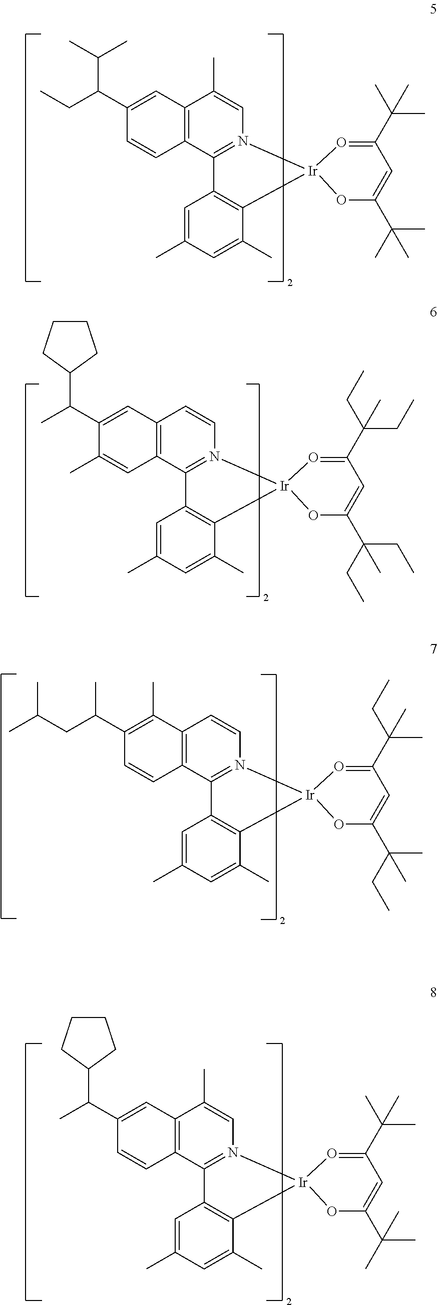

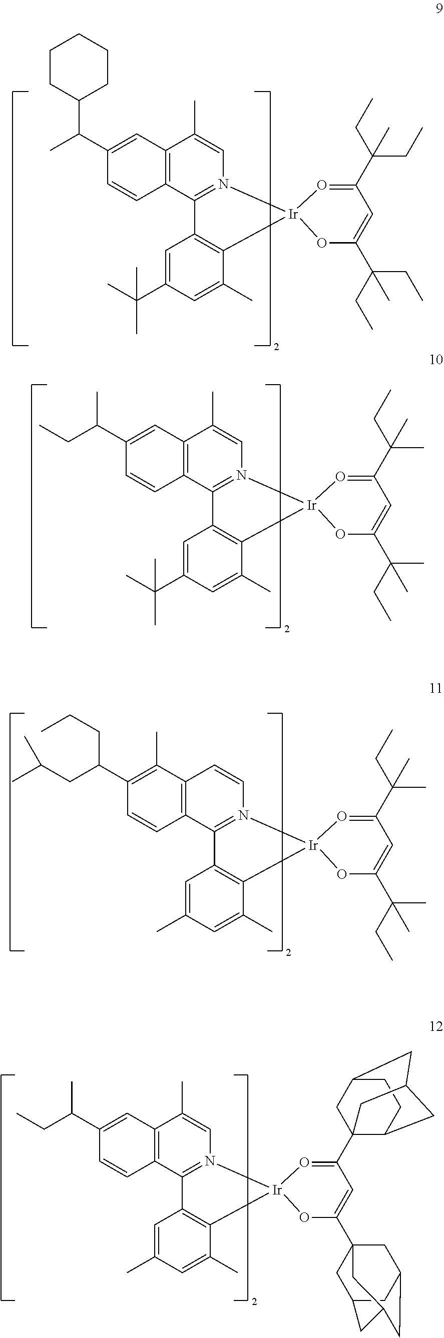

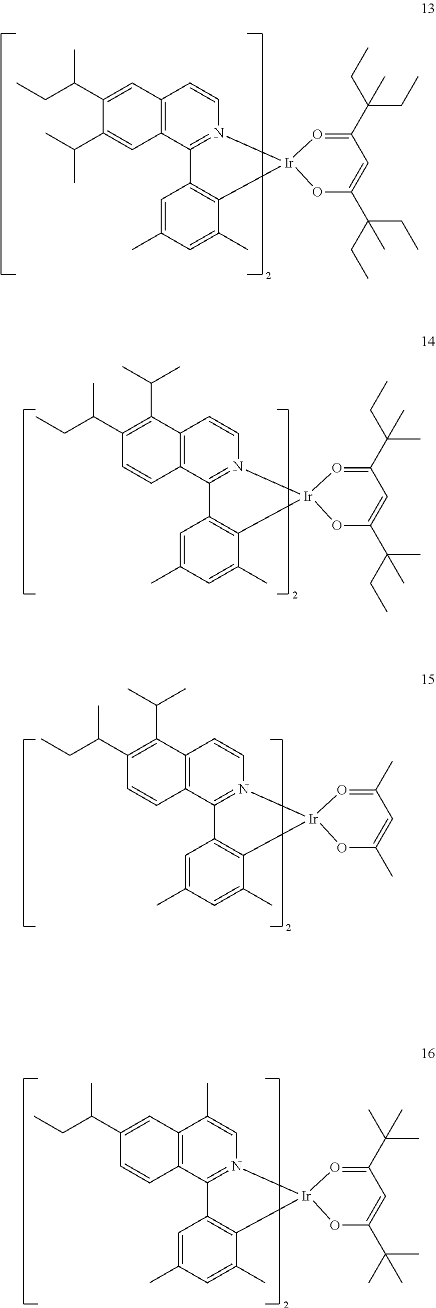

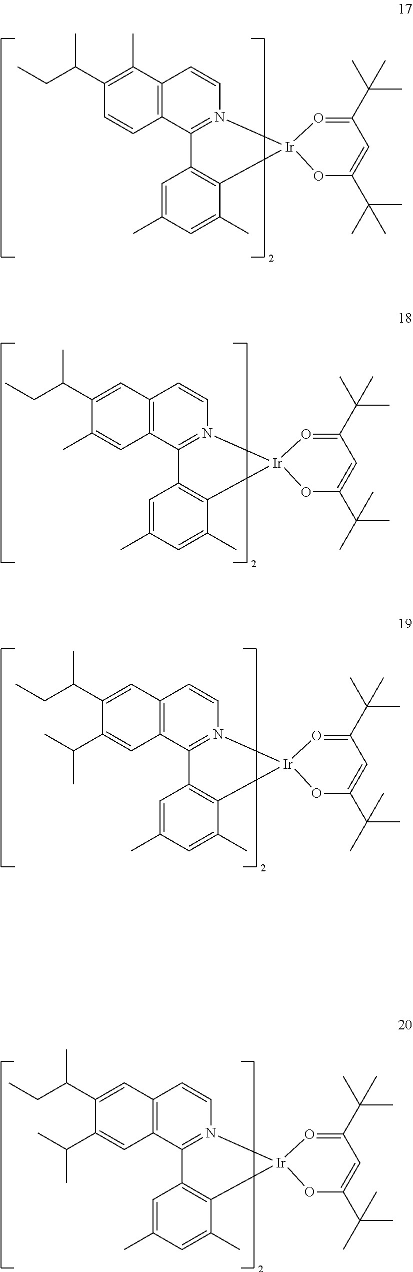

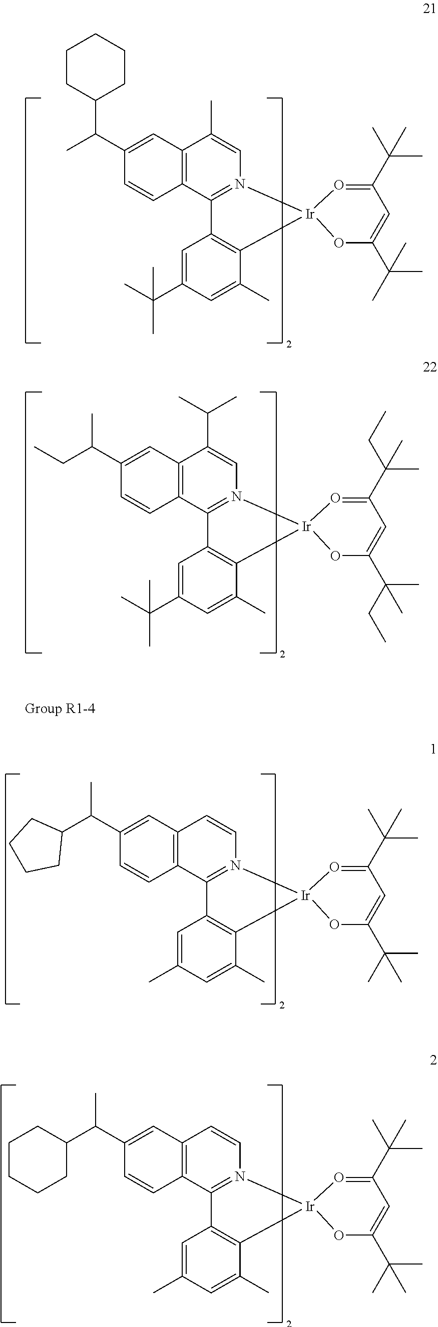

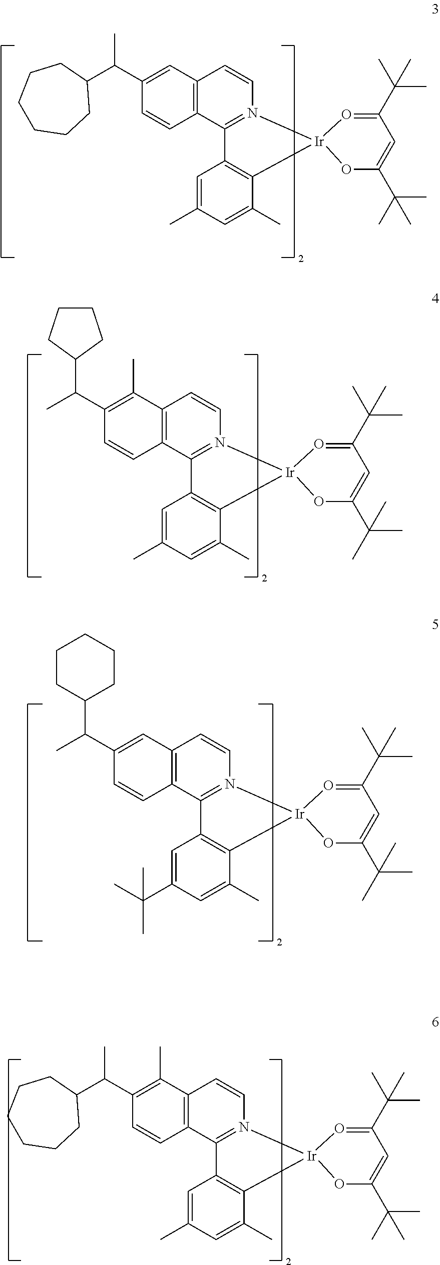

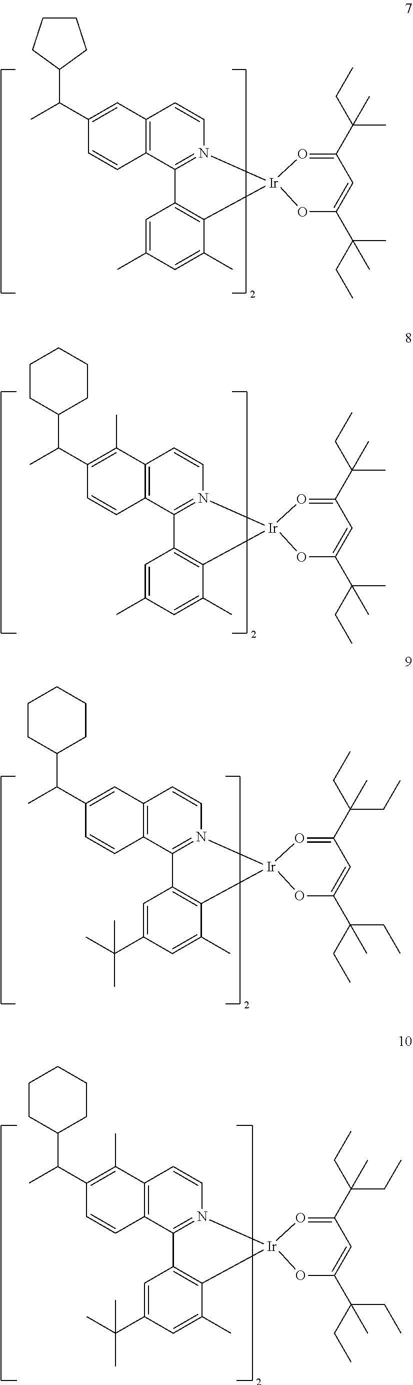

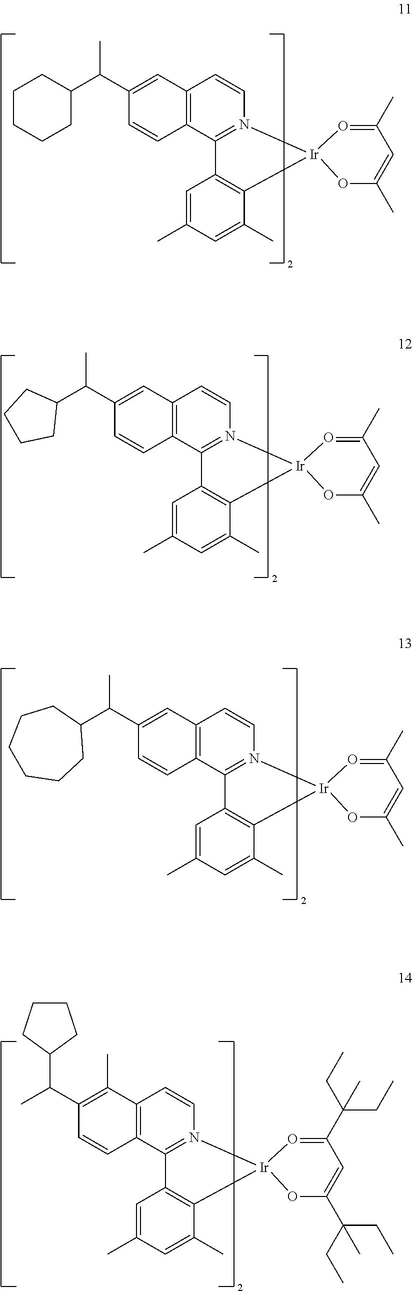

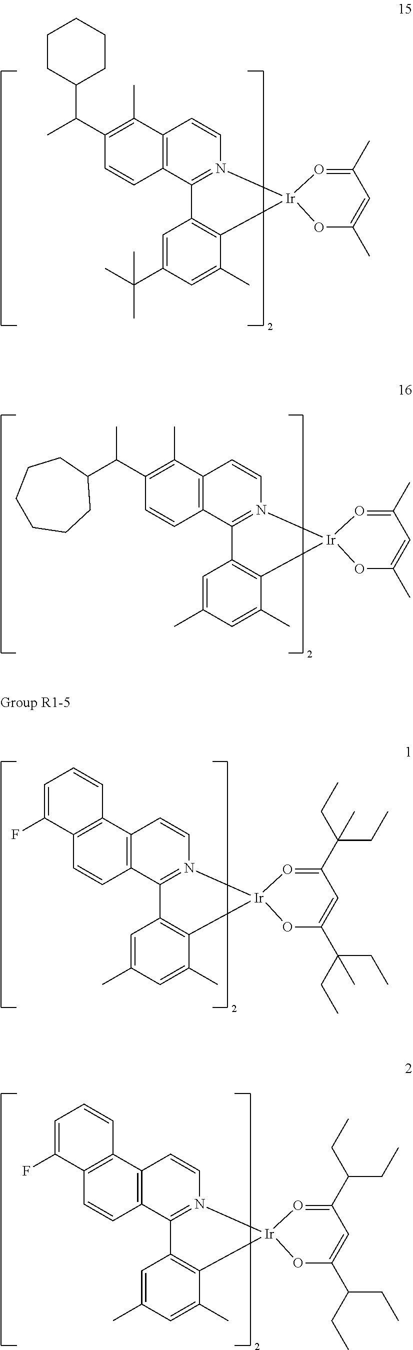

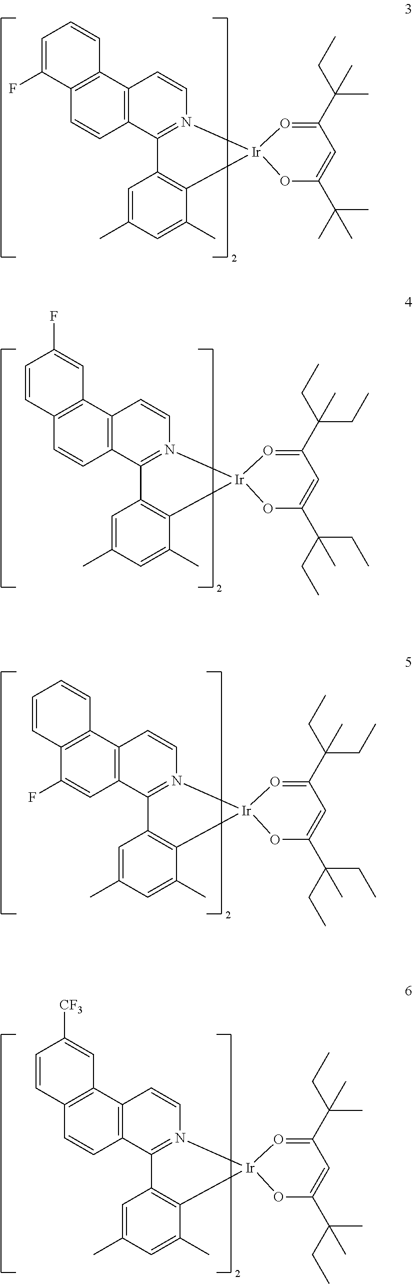

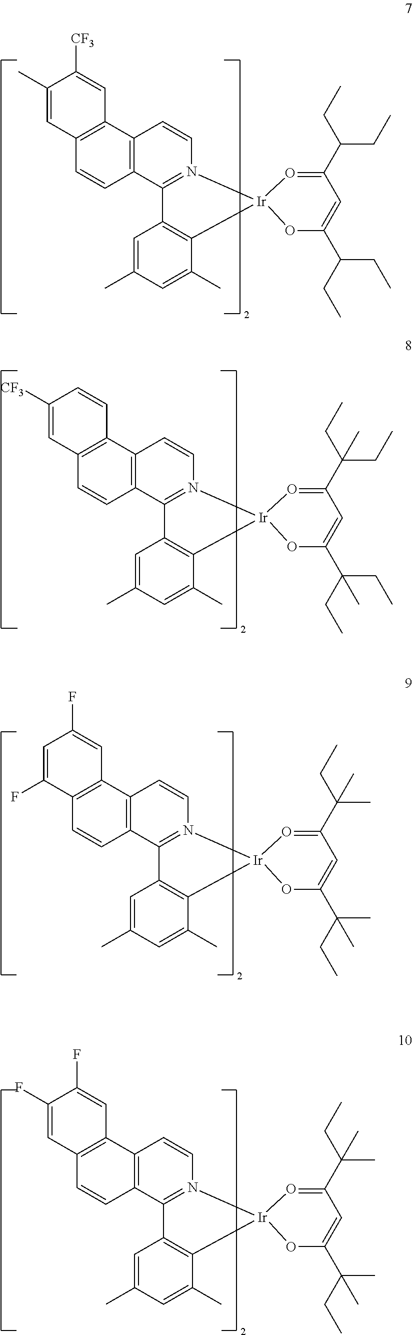

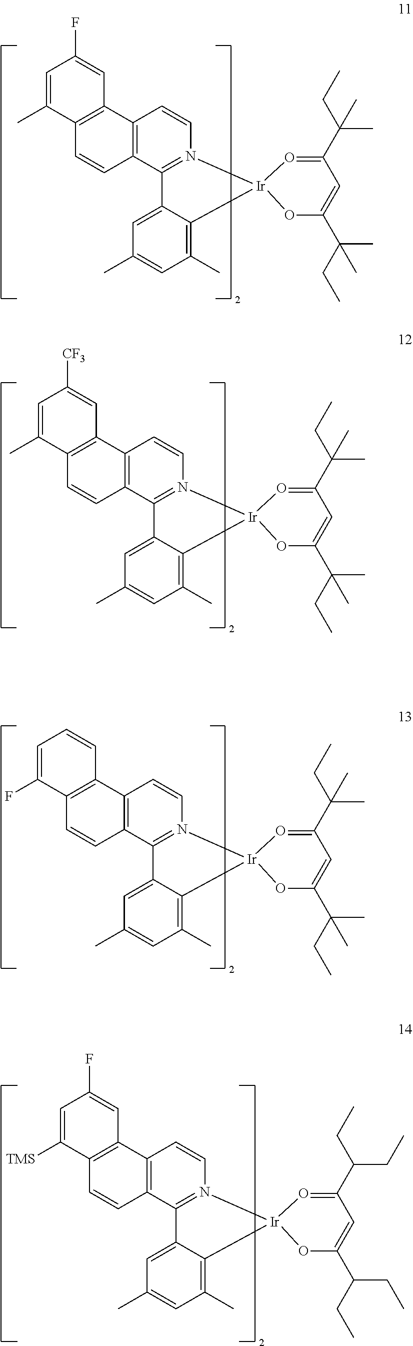

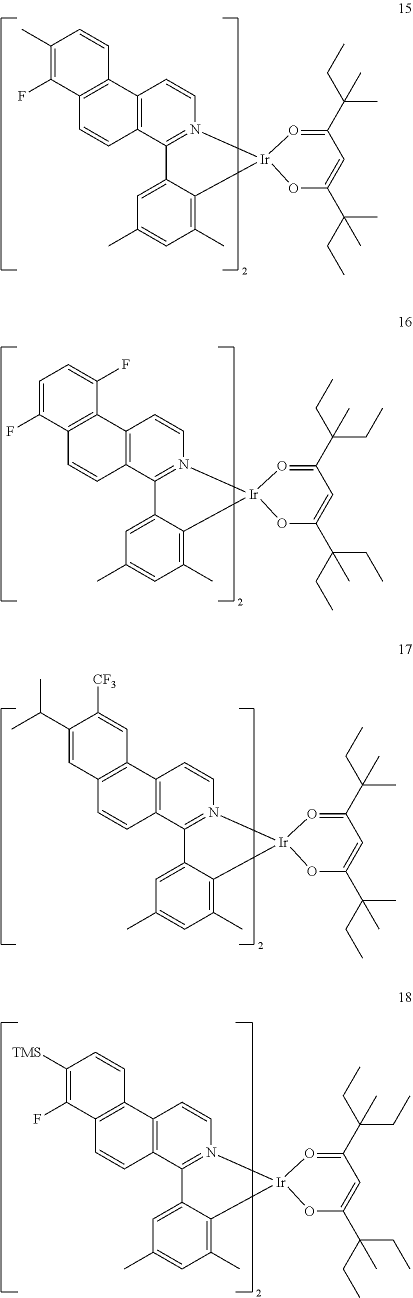

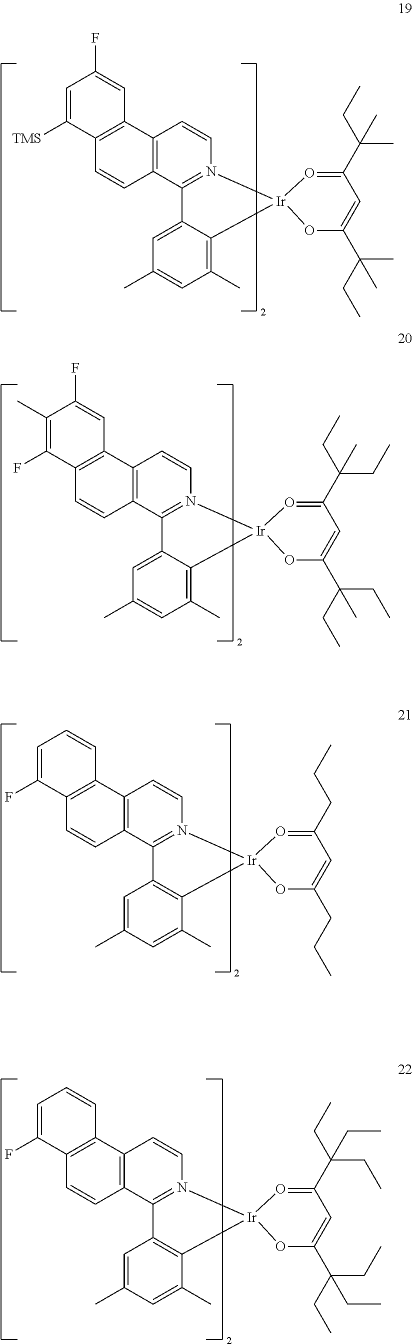

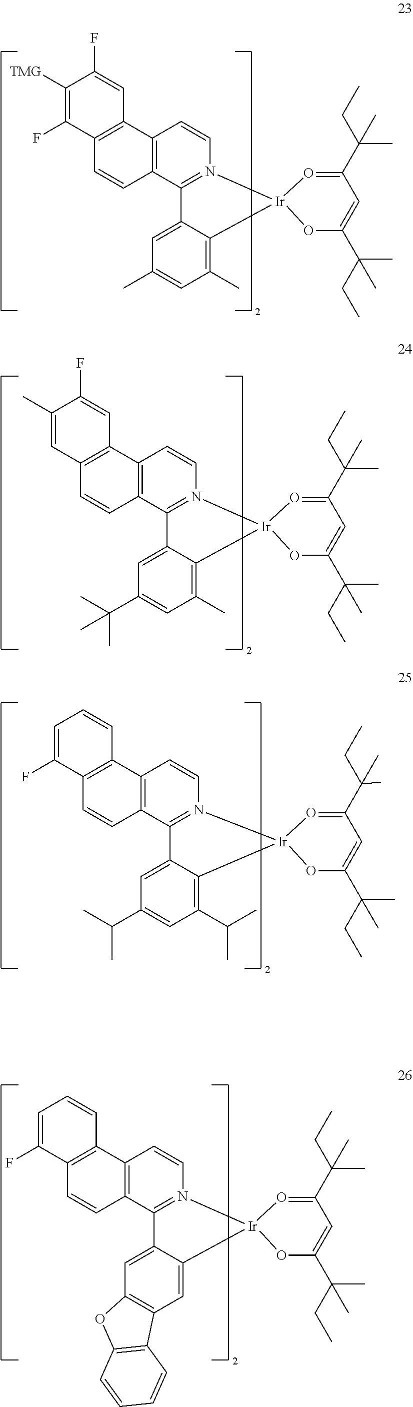

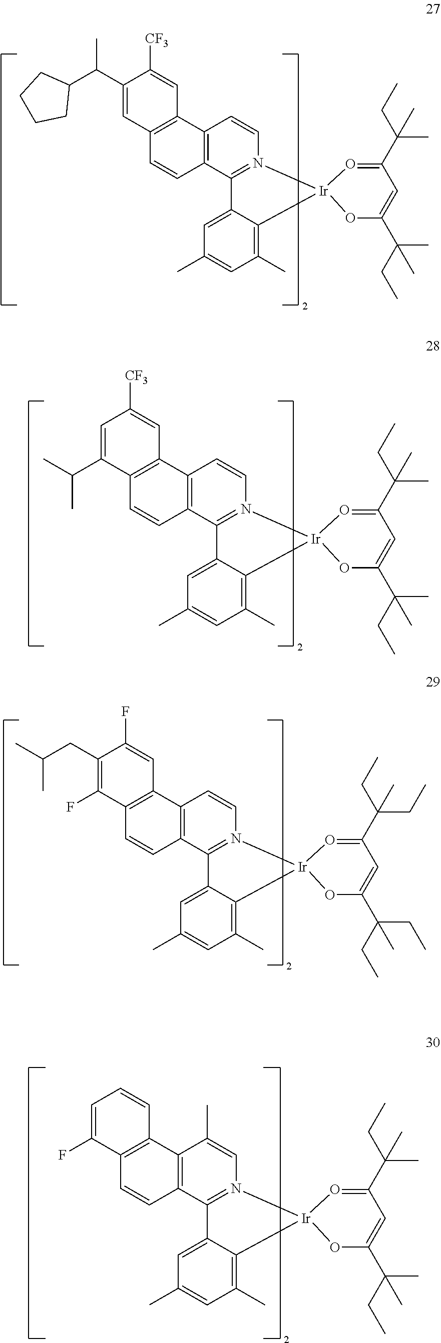

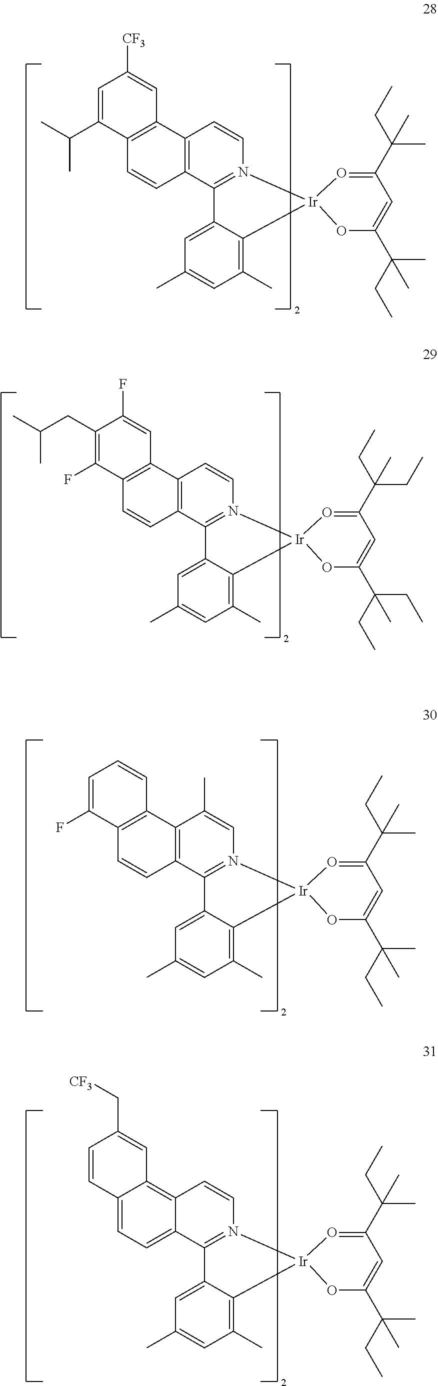

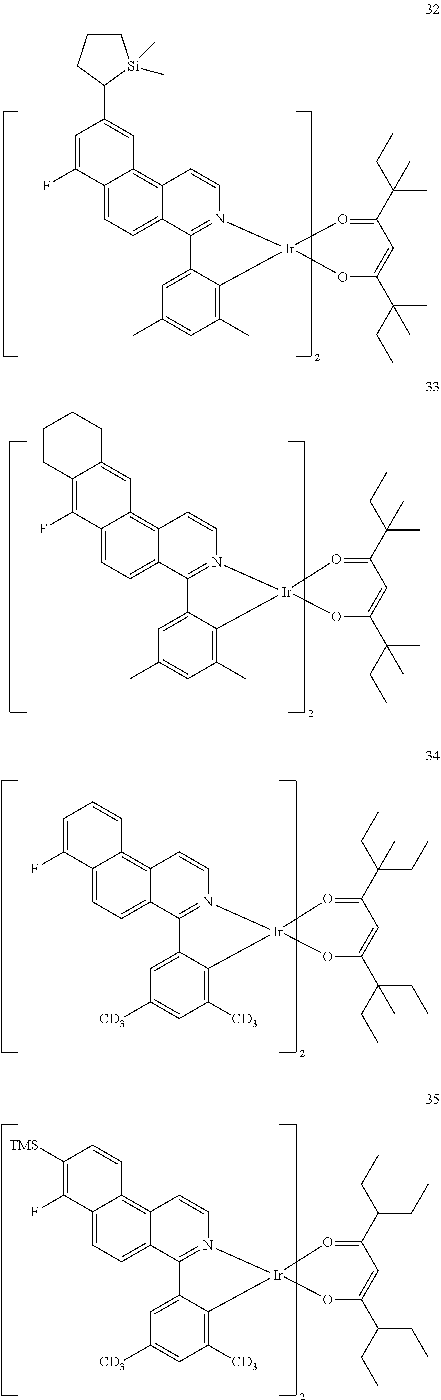

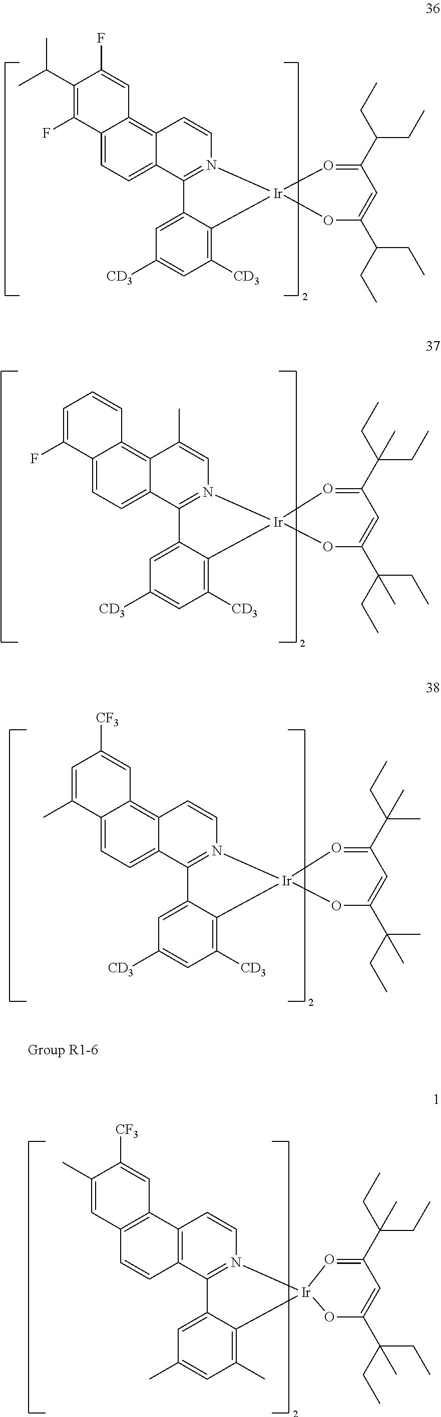

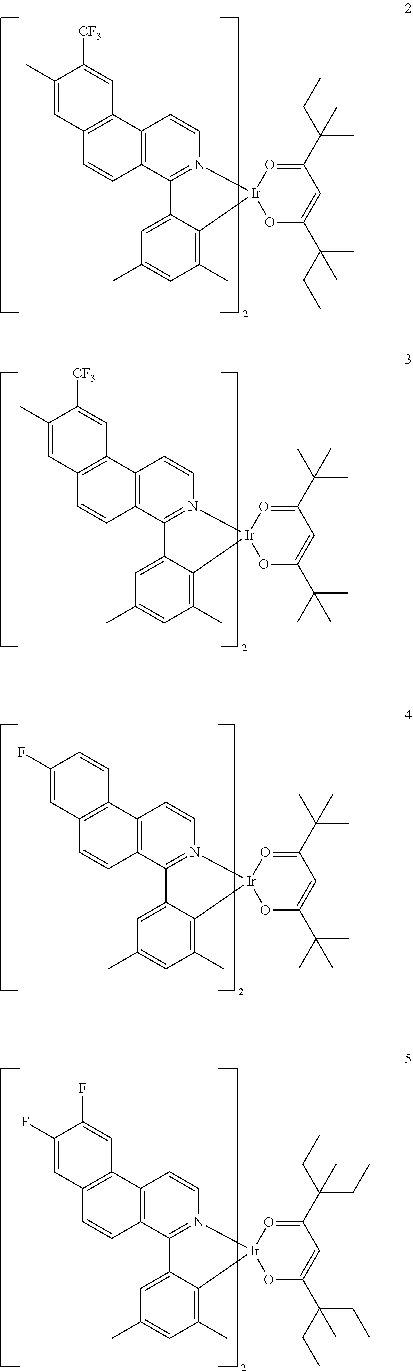

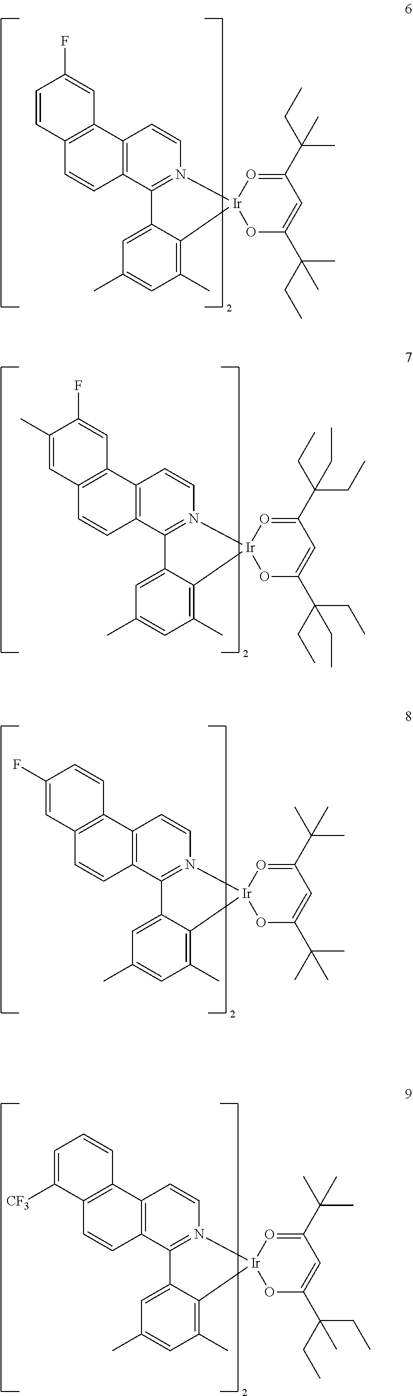

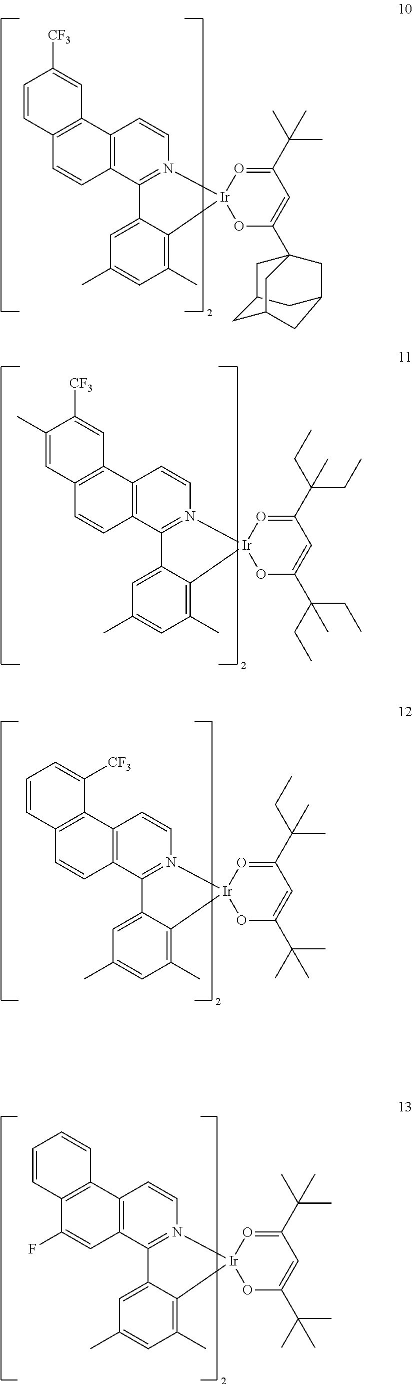

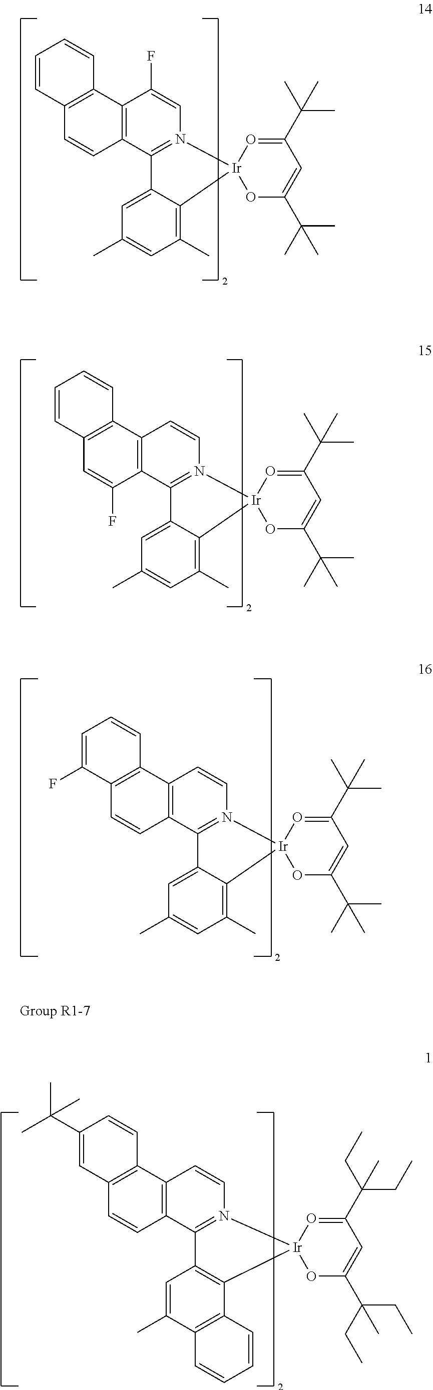

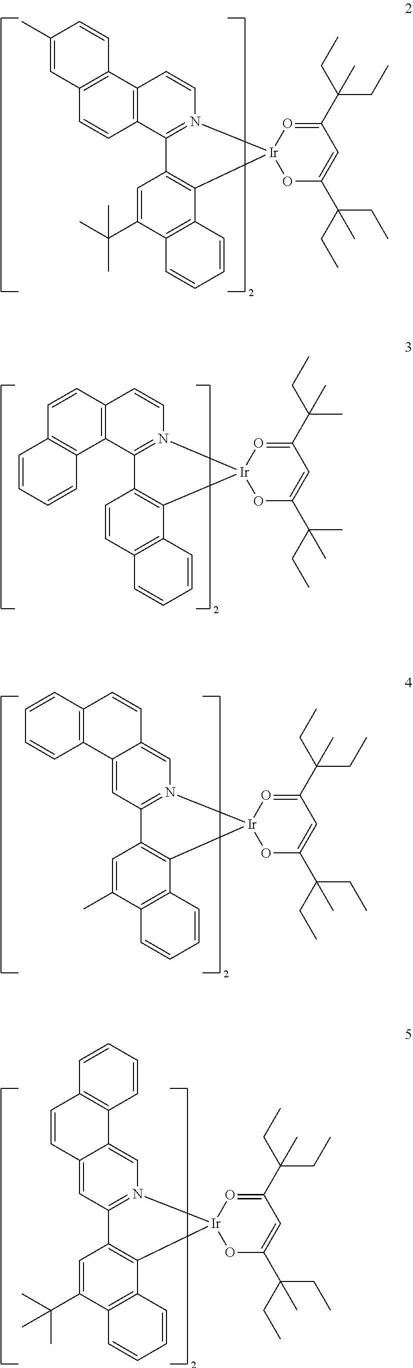

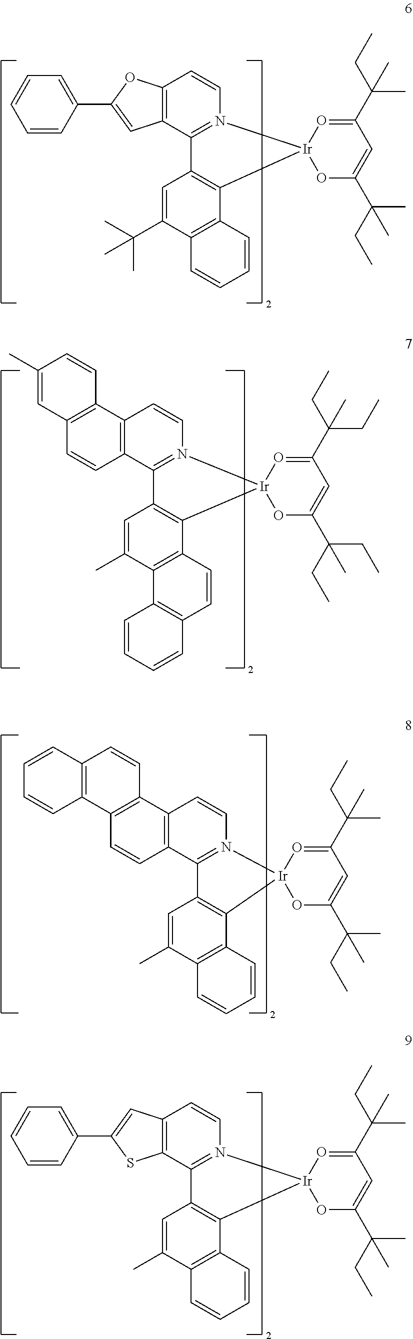

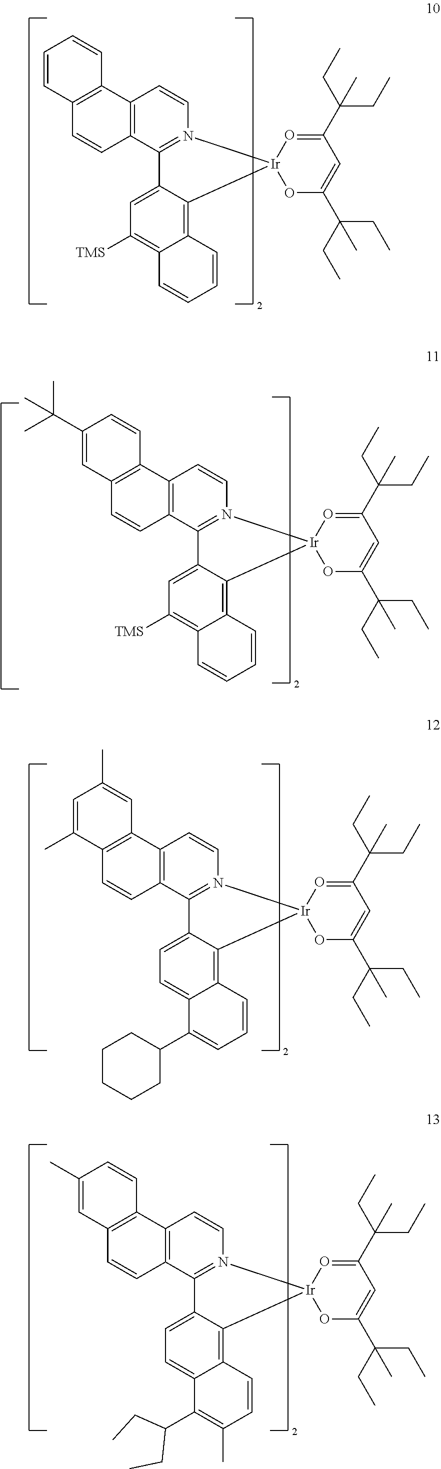

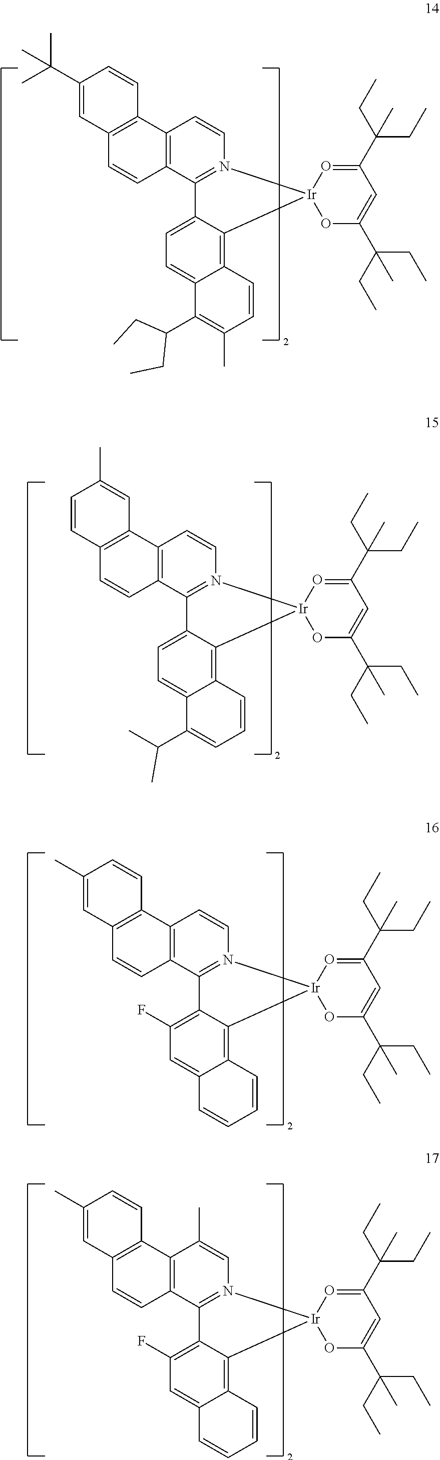

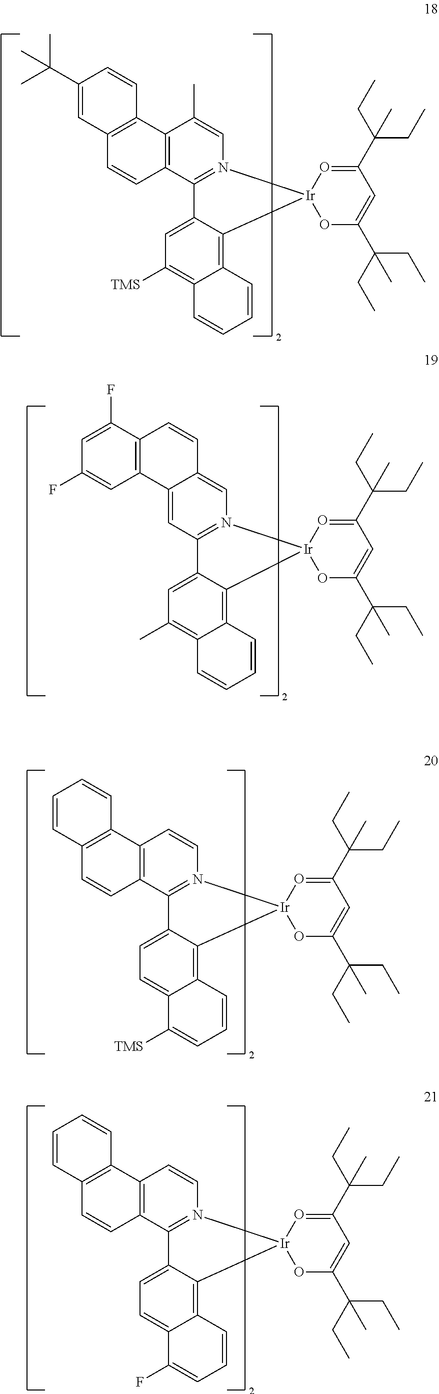

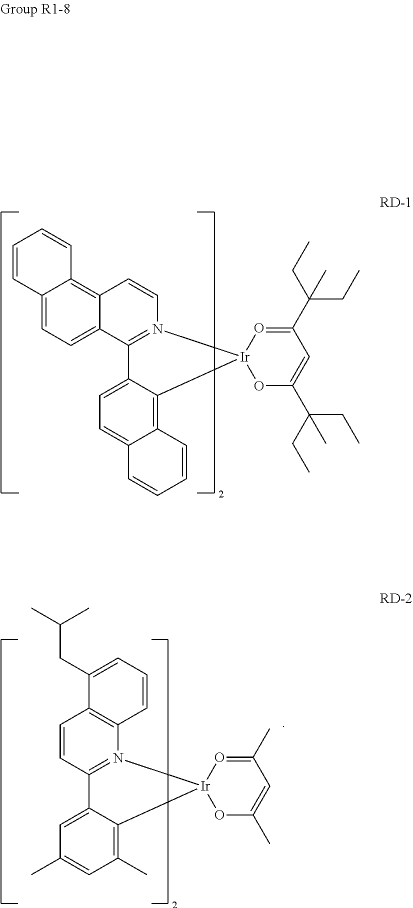

The composition as described above may emit light having excellent luminescence efficiency and lifespan (for example, blue light, green light, or red light). Accordingly, a layer including the composition, a light-emitting device including the composition, and an electronic apparatus including the light-emitting device may be provided.

According to another aspect, provided is a layer including the composition as described above.

In an embodiment, the layer may emit light having an emission peak wavelength in a range of about 480 nm to about 580 nm, for example, about 500 nm to about 570 nm.

In an embodiment, the layer may emit green light, yellowish green light, or yellow light.

In one or more embodiments, the layer may emit light having an emission peak wavelength in a range of about 510 nm to about 540 nm.

In one or more embodiments, the layer may emit light having an emission peak wavelength in a range of about 540 nm to about 570 nm.

In one or more embodiments, the layer may emit light having an emission peak wavelength in a range of about 570 nm to about 650 nm.

In an embodiment, the layer may emit red light.

In one or more embodiments, the layer may emit light having an emission peak wavelength in a range of about 400 nm to about 500 nm.

In an embodiment, the layer may emit blue light.

In one or more embodiments, the layer may not emit white light.

A weight ratio of the first compound to the second compound included in the layer may be in a range of about 90:10 to about 10:90, about 80:20 to about 20:80, about 70:30 to about 30:70, or about 60:40 to about 40:60.

In an embodiment, the weight ratio of the first compound to the second compound may be about 50:50, that is, 1:1.

The layer may be formed i) by co-deposition of the first compound and the second compound, or ii) by using a first mixture including the first compound and the second compound.

In one or more embodiments, the layer may include a host and a dopant, the host may not include a transition metal, and the dopant may include the composition including the first compound and the second compound. The layer may be formed i) by co-deposition of the host and the dopant, or ii) by using a second mixture including the host and the dopant.

A weight of the host in the layer may be greater than a weight of the dopant.

In an embodiment, a weight ratio of the host to the dopant in the layer may be in a range of about 99:1 to about 55:45, about 97:3 to about 60:40, or about 95:5 to about 70:30.

The host in the layer may include a hole-transporting compound, an electron-transporting compound, a bipolar compound, or a combination thereof.

According to another aspect, provided is a light-emitting device including a first electrode; a second electrode; and an organic layer including an emission layer located between the first electrode and the second electrode, wherein the organic layer includes the composition as described above.

Since the light-emitting device includes the composition including the first compound and the second compound as described above, the light-emitting device may have excellent driving voltage, excellent external quantum efficiency, and excellent lifespan characteristics. In addition, the light-emitting device may have an excellent side luminance ratio.

In an embodiment, the emission layer in the organic layer of the light-emitting device may include the composition including the first compound and the second compound.

In one or more embodiments, the emission layer may include a host and a dopant, the host may not include a transition metal, and the dopant may include the composition.

The host in the emission layer may include a hole-transporting compound, an electron-transporting compound, a bipolar compound, or a combination thereof.

In an embodiment, the host may include a hole-transporting compound and an electron-transporting compound, and the hole-transporting compound and the electron-transporting compound may be different from each other.

The emission layer may be formed by co-deposition of the host and the dopant, or by using a second mixture including the host and the dopant.

The emission layer may emit third light having a third spectrum, and λP(EML) indicates an emission peak wavelength (nm) in the third spectrum. In an embodiment,

λP(EML) may be evaluated from an electroluminescence spectrum of the light-emitting device.

Fourth light having a fourth spectrum may be extracted to the outside of the light-emitting device through the first electrode and/or the second electrode of the light-emitting device, and λP(OLED) indicates an emission peak wavelength (nm) in the fourth spectrum. In an embodiment, λP(OLED) may be evaluated from an electroluminescence spectrum of the light-emitting device.

In an embodiment, λP(EML) and λP(OLED) may each independently be in a range of about 500 nm to about 570 nm.

In one or more embodiments, λP(EML) and λP(OLED) may each independently be in a range of about 510 nm to about 540 nm.

In one or more embodiments, λP(EML) and λP(OLED) may each independently be in a range of about 540 nm to about 570 nm.

In one or more embodiments, the third light and the fourth light may each be green light, yellowish green light, or yellow light.

In one or more embodiments, λP(EML) and λP(OLED) may each independently be in a range of about 570 nm to about 650 nm.

In one or more embodiments, the third light and the fourth light may each be red light.

In one or more embodiments, λP(EML) and λP(OLED) may each independently be in a range of about 400 nm to about 500 nm.

In one or more embodiments, the third light and the fourth light may each be blue light.

In one or more embodiments, the third light and the fourth light may not be white light.

In one or more embodiments, the third spectrum i) may include a main emission peak having λP(EML) in a range of about 500 nm to about 570 nm, and ii) may not include an additional emission peak having an emission peak wavelength greater than or equal to λP(EML)+50 nm, or less than or equal to λP(EML)-50 nm.

In one or more embodiments, the third spectrum i) may include a main emission peak having λP(EML) in a range of about 500 nm to about 570 nm, and ii) may not include an additional emission peak having an emission peak wavelength of red light and/or blue light region.

In one or more embodiments, the fourth spectrum i) may include a main emission peak having λP(OLED) in a range of about 500 nm to about 570 nm, and ii) may not include an additional emission peak having an emission peak wavelength greater than or equal to λP(OLED)+50 nm, or less than or equal to λP(OLED)-50 nm.

In one or more embodiments, the fourth spectrum i) may include a main emission peak having λP(OLED) in a range of about 500 nm to about 570 nm, and ii) may not include an additional emission peak having an emission peak wavelength of red light and/or blue light region.

In one or more embodiments, the third spectrum i) may include a main emission peak having λP(EML) in a range of about 570 nm to about 650 nm, and ii) may not include an additional emission peak having an emission peak wavelength greater than or equal to λP(EML)+50 nm, or less than or equal to λP(EML)-50 nm.

In one or more embodiments, the third spectrum i) may include a main emission peak having λP(EML) in a range of about 570 nm to about 650 nm, and ii) may not include an additional emission peak having an emission peak wavelength of green light and/or blue light region.

In one or more embodiments, the fourth spectrum i) may include a main emission peak having λP(OLED) in a range of about 570 nm to about 650 nm, and ii) may not include an additional emission peak having an emission peak wavelength greater than or equal to λP(OLED)+50 nm, or less than or equal to λP(OLED)-50 nm.

In one or more embodiments, the fourth spectrum i) may include a main emission peak having λP(OLED) in a range of about 570 nm to about 650 nm, and ii) may not include an additional emission peak having an emission peak wavelength of green light and/or blue light region.

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In an embodiment, in the organic light-emitting device, the first electrode may be an anode, the second electrode may be a cathode, the organic layer may further include a hole transport region located between the first electrode and the emission layer and an electron transport region located between the emission layer and the second electrode, the hole transport region may include a hole injection layer, a hole transport layer, an electron blocking layer, a buffer layer, or a combination thereof, and the electron transport region may include a hole blocking layer, an electron transport layer, an electron injection layer, or a combination thereof.

The term “organic layer” used herein refers to a single layer and/or a plurality of layers between the first electrode and the second electrode of the organic light-emitting device. The “organic layer” may include, in addition to an organic compound, an organometallic complex including metal.

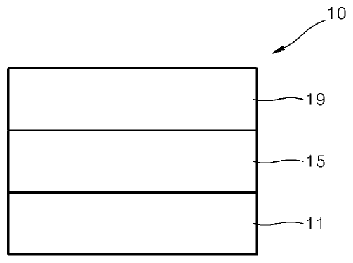

The FIG. 1s a schematic cross-sectional view of an organic light-emitting device 10 according to an embodiment. Hereinafter, the structure and manufacturing method of the organic light-emitting device 10 according to an embodiment of the present disclosure will be described in connection with the FIGURE. The organic light-emitting device 10 has a structure in which a first electrode 11, an organic layer 15, and a second electrode 19 are sequentially stacked.

A substrate may be additionally located under the first electrode 11 or above the second electrode 19. For use as the substrate, any substrate that is used in organic light-emitting devices available in the art may be used, and the substrate may be a glass substrate or a transparent plastic substrate, each having excellent mechanical strength, thermal stability, transparency, surface smoothness, ease of handling, and water resistance.

In an embodiment, the first electrode 11 may be formed by depositing or sputtering a material for forming the first electrode 11 on the substrate. The first electrode 11 may be an anode. The material for forming the first electrode 11 may include materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), silver (Ag), aluminum-lithium (Al—Li), calcium (Ca), magnesium-indium (Mg—In), or magnesium-silver (Mg—Ag).

The first electrode 11 may have a single-layered structure or a multi-layered structure including two or more layers. In an embodiment, the first electrode 11 may have a three-layered structure of ITO/Ag/ITO.

The organic layer 15 is located on the first electrode 11.

The organic layer 15 may include a hole transport region, an emission layer, and an electron transport region.

The hole transport region may be located between the first electrode 11 and the emission layer.

The hole transport region may include a hole injection layer, a hole transport layer, an electron blocking layer, a buffer layer, or a combination thereof.

The hole transport region may include only either a hole injection layer, or a hole transport layer. In one or more embodiments, the hole transport region may have a hole injection layer/hole transport layer structure, or a hole injection layer/hole transport layer/electron blocking layer structure, wherein, for each structure, each layer is sequentially stacked in this stated order from the first electrode 11.

When the hole transport region includes a hole injection layer, the hole injection layer may be formed on the first electrode 11 by using one or more suitable methods, for example, vacuum deposition, spin coating, casting, and/or Langmuir-Blodgett (L-B) deposition.

When the hole injection layer is formed by vacuum deposition, the deposition conditions may vary according to a material that is used to form the hole injection layer, and a structure and thermal properties of the hole injection layer. For example, a deposition temperature may be from about 100° C. to about 500° C., a vacuum pressure may be from about 10⁻⁸ torr to about 10⁻³ torr, and a deposition rate may be from about 0.01 angstroms per second (Å/sec) to about 100 Å/sec.

When the hole injection layer is formed using spin coating, the coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C.

The conditions for forming the hole transport layer and the electron blocking layer may be similar to the conditions for forming the hole injection layer.

The hole transport region may include 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(naphthalene-1-yl)-N,N′-diphenyl-benzidine (NPB), 3-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202 below, or a combination thereof:

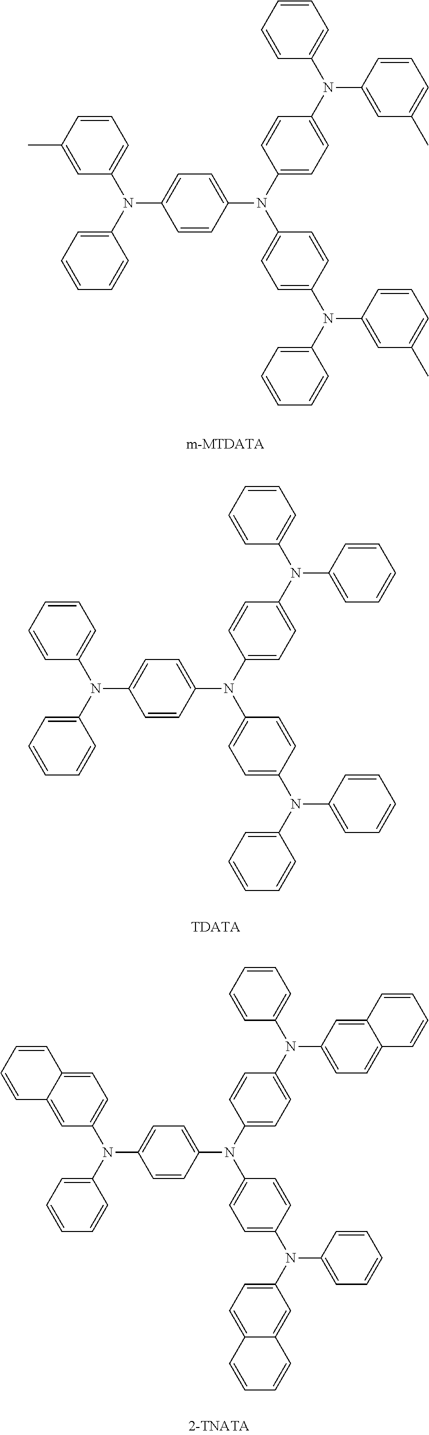

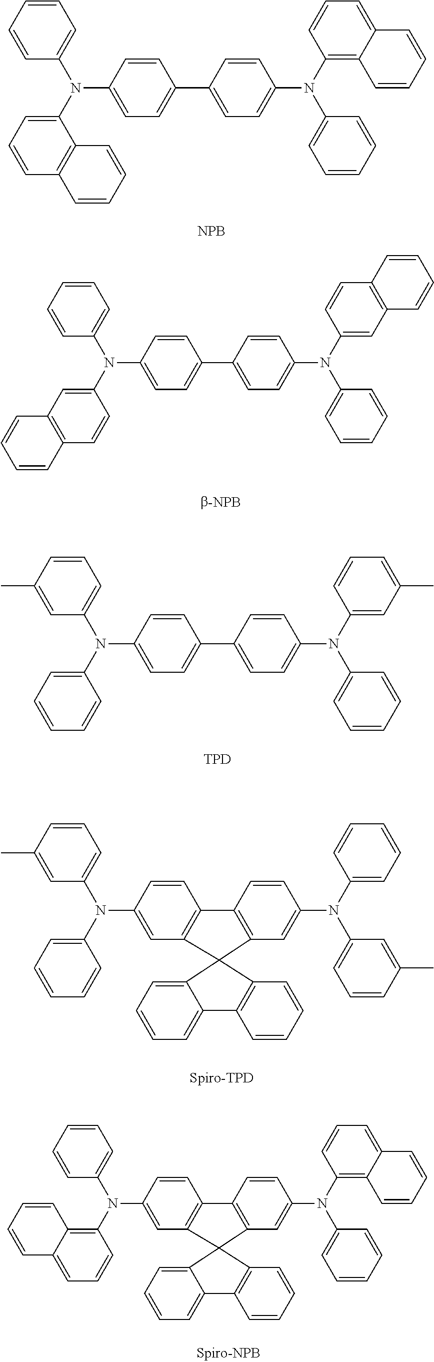

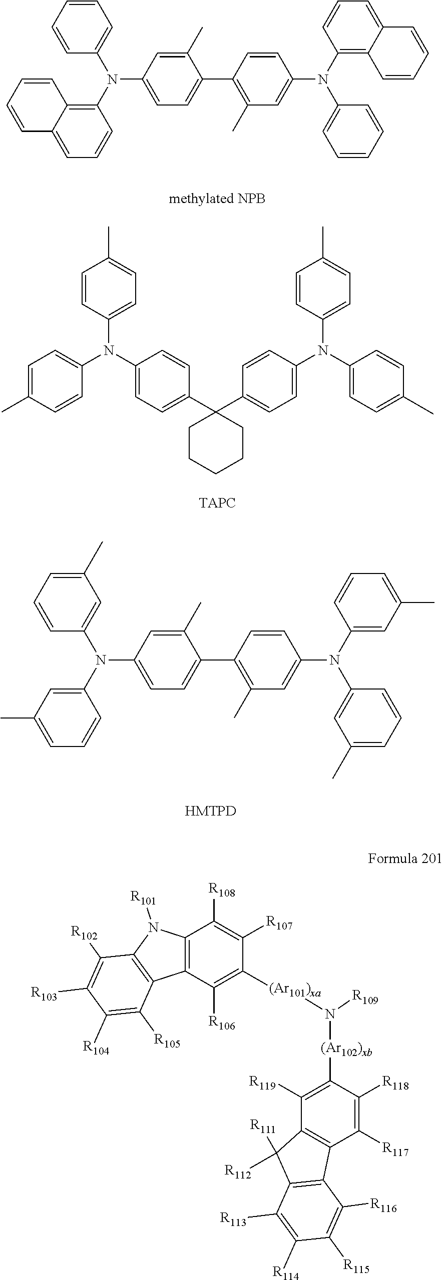

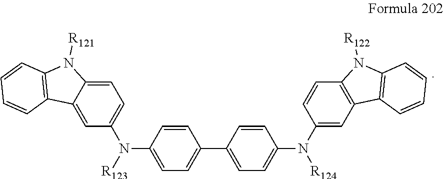

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with at least one of deuterium, —F, —Cl, —Br, —I, a hydroxyl group, a cyano group, a nitro group, an amino group, a C₁-C₈₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

xa and xb in Formula 201 may each independently be an integer from 0 to 5, or 0, 1, or 2. In an embodiment, xa may be 1, and xb may be 0.

R₁₀₁ to R₁₀₈, R₁₁₁ to R₁₁₉, and R₁₂₁ to R₁₂₄ in Formulae 201 and 202 may each independently be:

hydrogen, deuterium, —F, —Cl, —Br, —I, a hydroxyl group, a cyano group, a nitro group, an amino group, a C₁-C₁₀ alkyl group (for example, a methyl group, an ethyl group, a propyl group, a butyl group, a pentyl group, a hexyl group, or the like), a C₁-C₁₀ alkoxy group (for example, a methoxy group, an ethoxy group, a propoxy group, a butoxy group, a pentoxy group, or the like), or a C₁-C₁₀ alkylthio group;

a C₁-C₁₀ alkyl group, a C₁-C₁₀ alkoxy group, or a C₁-C₆₀ alkylthio group, each unsubstituted or substituted with at least one of deuterium, —F, —Cl, —Br, —I, a hydroxyl group, a cyano group, a nitro group, an amino group, or a combination thereof; or

a phenyl group, a naphthyl group, an anthracenyl group, a fluorenyl group, or a pyrenyl group, each unsubstituted or substituted with at least one of deuterium, —F, —Cl, —Br, —I, a hydroxyl group, a cyano group, a nitro group, an amino group, a C₁-C₁₀ alkyl group, a C₁-C₁₀ alkoxy group, a C₁-C₁₀ alkylthio group, or a combination thereof.

R₁₀₉ in Formula 201 may be a phenyl group, a naphthyl group, an anthracenyl group, or a pyridinyl group, each unsubstituted or substituted with at least one of deuterium, —F, —Cl, —Br, —I, a hydroxyl group, a cyano group, a nitro group, an amino group, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one embodiment, the compound represented by Formula 201 may be represented by Formula 201A:

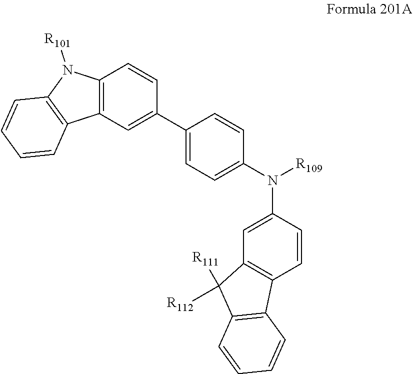

wherein, in Formula 201A, R₁₀₁, R₁₁₁, R₁₁₂, and R₁₀₉ are as described hereinabove.

In an embodiment, the hole transport region may include one of Compounds HT1 to HT21 or a combination thereof:

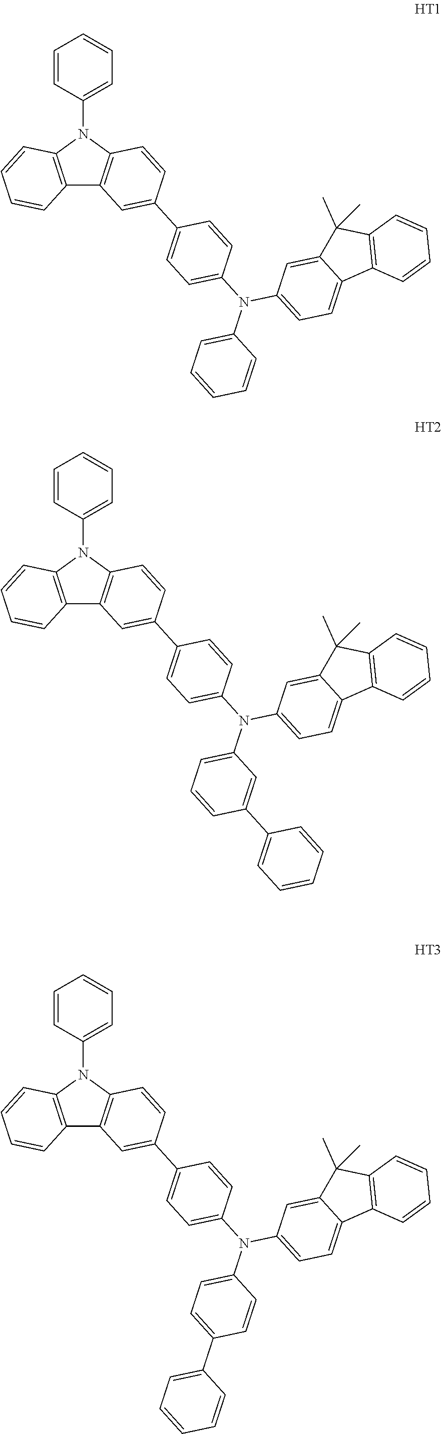 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

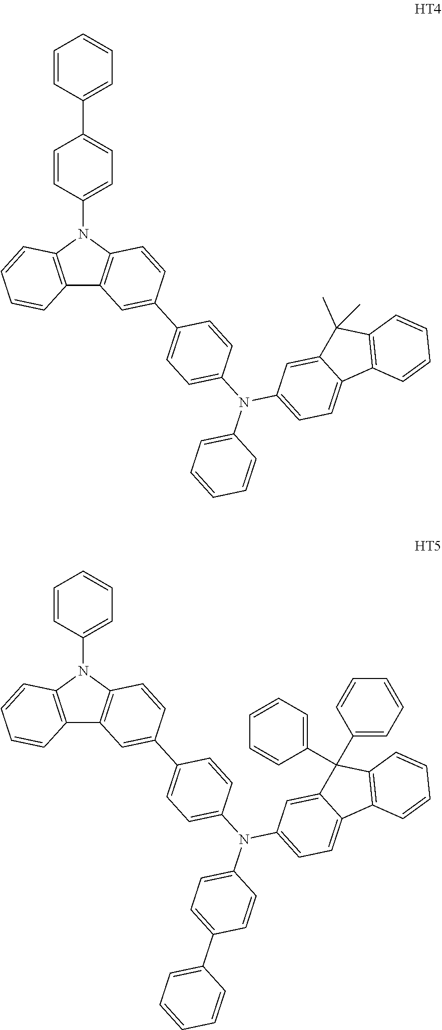 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

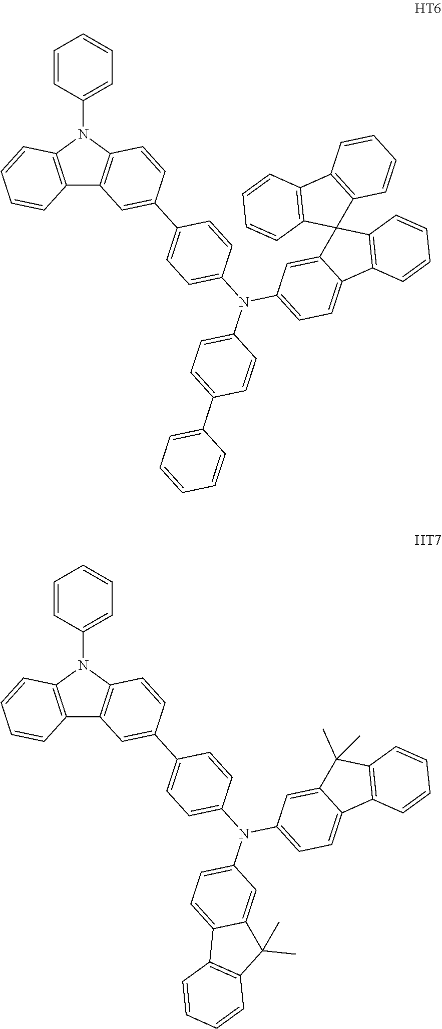 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

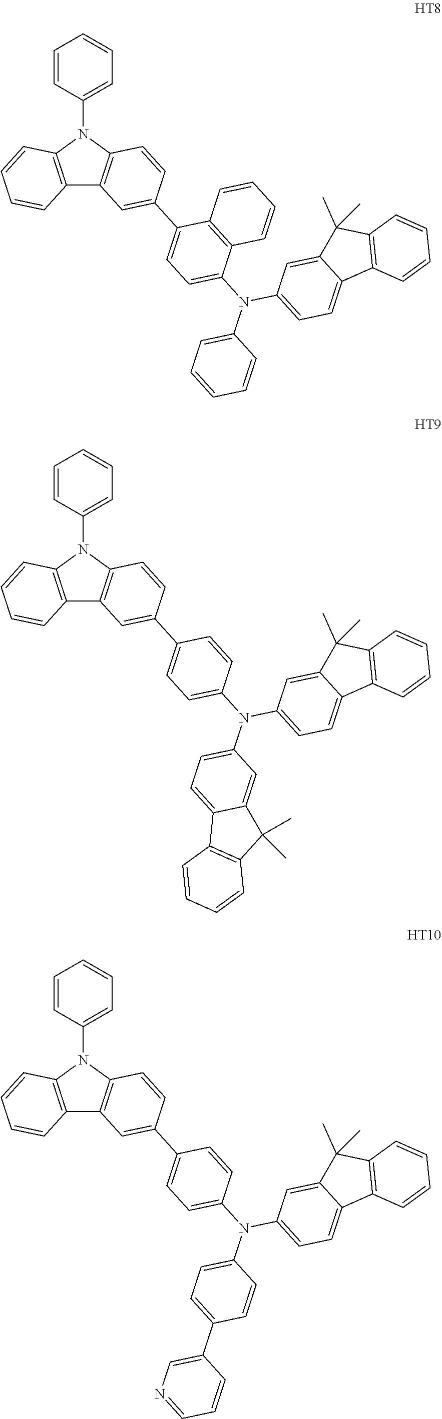 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

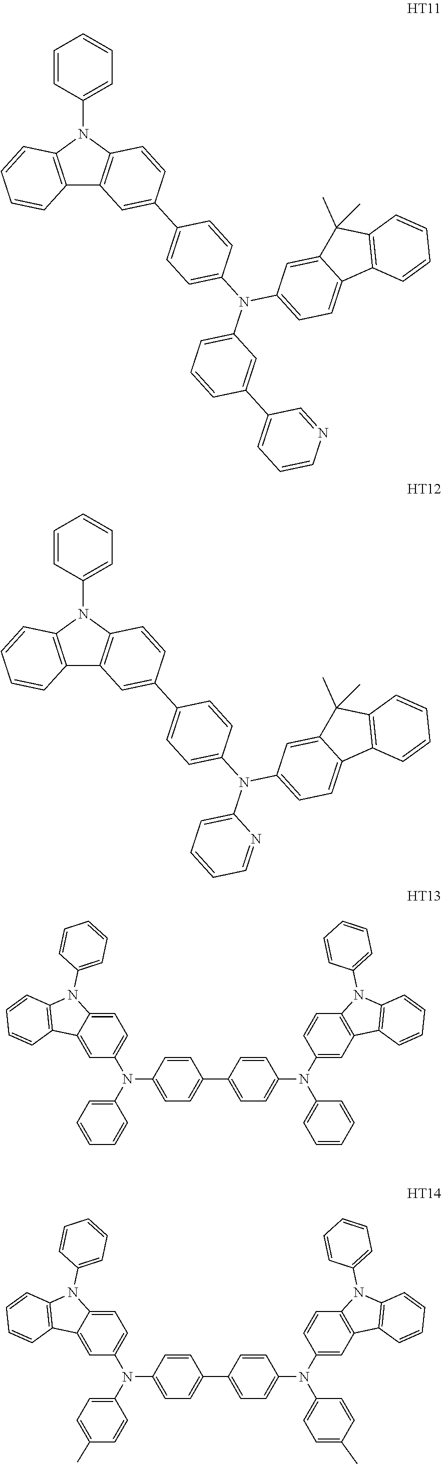 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

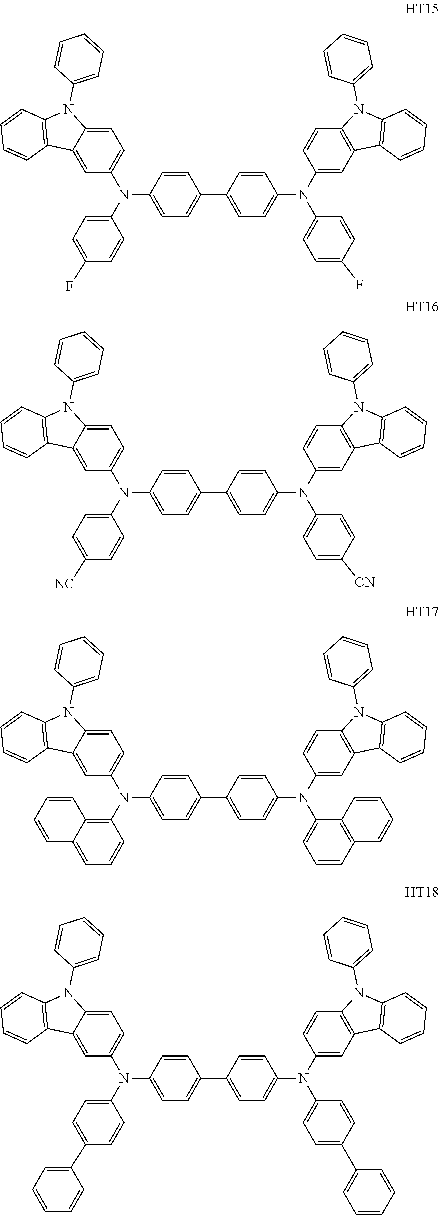 [SMILES: Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

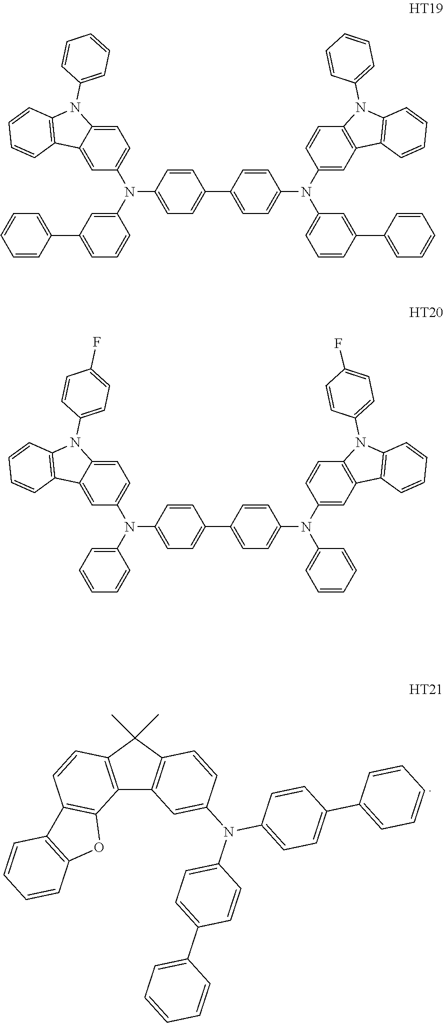 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccc(N(c3ccc(-c4ccccc4)cc3)c3ccc(-c4ccccc4)cc3)cc2-c2c1ccc1c2oc2ccccc21]

A thickness of the hole transport region may be in a range of about 100 Å to about 10,000 Å, for example, about 100 Å to about 1,000 Å. When the hole transport region includes a hole injection layer, a hole transport layer, an electron blocking layer, or a combination thereof, the thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole-transporting characteristics may be obtained without a substantial increase in driving voltage.

The hole transport region may further include, in addition to these materials, a charge-generation material to improve conductivity. The charge-generation material may be homogeneously or non-homogeneously dispersed in the hole transport region.

The charge-generation material may be, for example, a p-dopant. The p-dopant may be a quinone derivative, a metal oxide, a cyano group-containing compound, or a combination thereof. In an embodiment, the p-dopant may be: a quinone derivative such as tetracyanoquinodimethane (TCNQ), 2,3,5,6-tetrafluoro-tetracyano-1,4-benzoquinonedimethane (F4-TCNQ), or F6-TCNNQ; a metal oxide, such as tungsten oxide or molybdenum oxide; a cyano group-containing compound, such as Compound HT-D1; or a combination thereof:

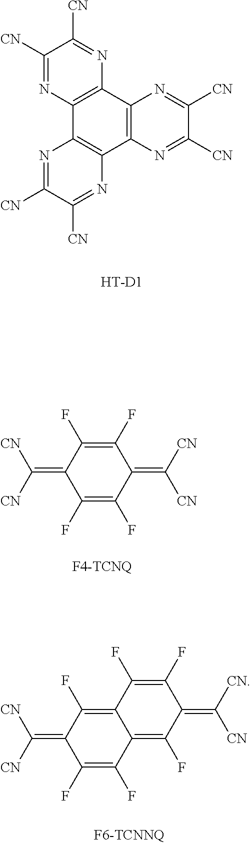

The hole transport region may further include a buffer layer.

The buffer layer may compensate for an optical resonance distance according to a wavelength of light emitted from the emission layer, and thus, efficiency of a formed organic light-emitting device may be improved.

Meanwhile, when the hole transport region includes an electron blocking layer, a material for forming the electron blocking layer may include a material that is used in the hole transport region as described above, a host material described below, or a combination thereof. In an embodiment, when the hole transport region includes an electron blocking layer, mCP described below, Compound H-H1, or a combination thereof may be used as the material for forming the electron blocking layer.

Then, an emission layer may be formed on the hole transport region by vacuum deposition, spin coating, casting, LB deposition, or the like. When the emission layer is formed by vacuum deposition or spin coating, deposition or coating conditions may be similar to those applied in forming the hole injection layer although the deposition or coating conditions may vary according to a material used to form the emission layer.

The emission layer may include the composition including the first compound and the second compound as described herein. In one or more embodiments, the emission layer may include a layer including the composition including the first compound and the second compound as described herein.

In an embodiment, the emission layer may include a host and a dopant, the host may not include a transition metal, and the dopant may include the composition including the first compound and the second compound as described herein.

The host may include 1,3,5-tri(1-phenyl-1H-benzo[d]imidazol-2-yl)phenyl (TPBi), 3-tert-butyl-9,10-di(naphth-2-yl)anthracene (TBADN), 9,10-di(naphthalene-2-yl)anthracene (ADN, also referred to as “DNA”), 4,4′-bis(N-carbazolyl)-1,1′-biphenyl (CBP), 4,4′-bis(9-carbazolyl)-2,2′-dimethyl-biphenyl (CDBP), TCP, mCP, Compound H50, Compound H51, Compound H-H1, Compound H-H2, Compound H52, or a combination thereof:

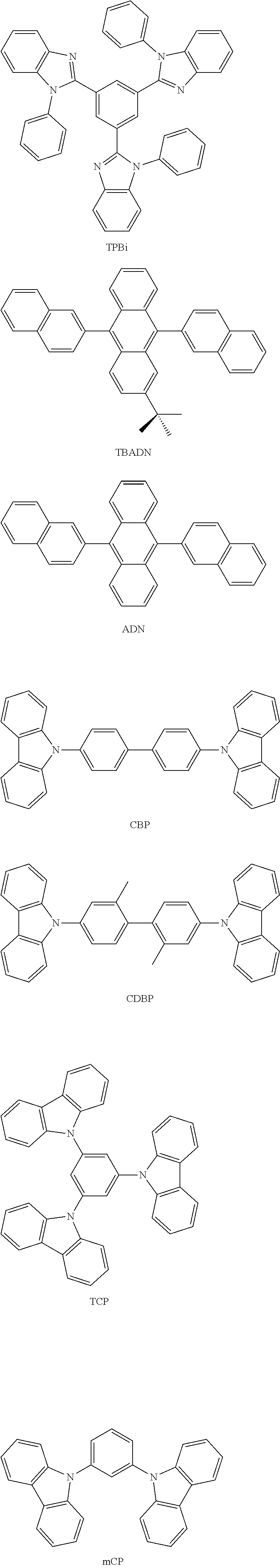

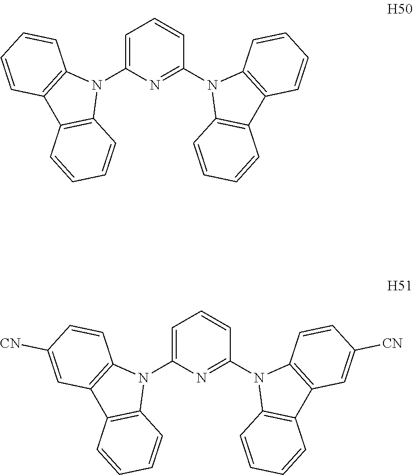

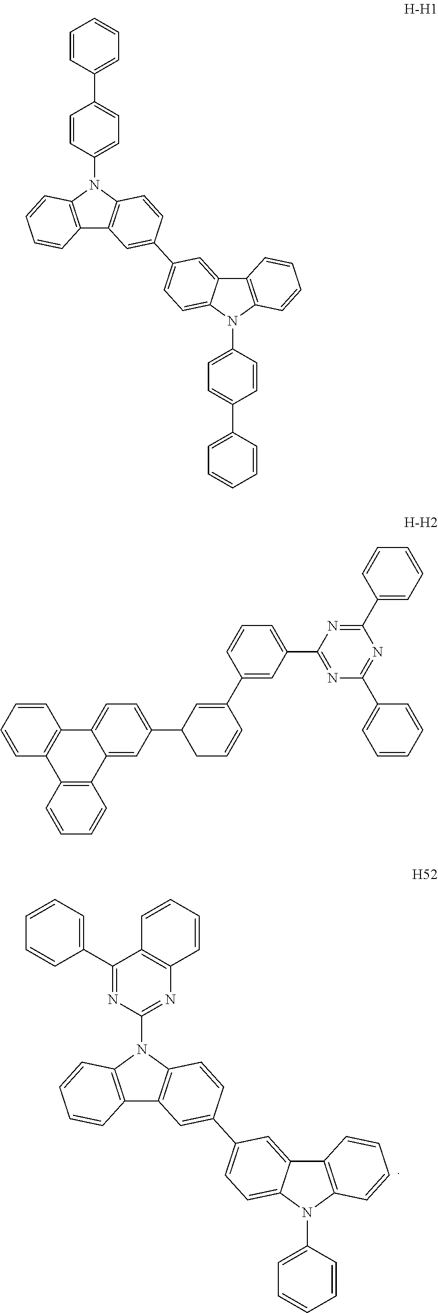 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; C1=CC(c2cccc(-c3nc(-c4ccccc4)nc(-c4ccccc4)n3)c2)=CC(c2ccc3c4ccccc4c4ccccc4c3c2)C1 ; c1ccc(-c2nc(-n3c4ccccc4c4cc(-c5ccc6c(c5)c5ccccc5n6-c5ccccc5)ccc43)nc3ccccc23)cc1]

When the organic light-emitting device is a full-color organic light-emitting device, the emission layer may be patterned into a red emission layer, a green emission layer, and/or a blue emission layer.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

An electron transport region may be located on the emission layer.

The electron transport region may include a hole blocking layer, an electron transport layer, an electron injection layer, or a combination thereof.

In an embodiment, the electron transport region may have a hole blocking layer/electron transport layer/electron injection layer structure or an electron transport layer/electron injection layer structure. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, 2,9-dimethyl-4,7-diphenyl-1,10-phenanthroline (BCP), 4,7-diphenyl-1,10-phenanthroline (Bphen), bis(2-methyl-8-quinolinolato-N1,O8)-(1,1′-biphenyl-4-olato)aluminum (Balq), or a combination thereof:

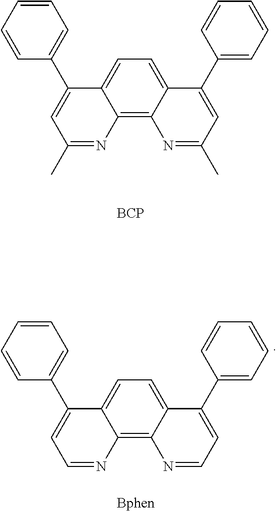 [SMILES: Cc1cc(-c2ccccc2)c2ccc3c(-c4ccccc4)cc(C)nc3c2n1 ; "BCP" ; c1ccc(-c2ccnc3c2ccc2c(-c4ccccc4)ccnc23)cc1]

A thickness of the hole blocking layer may be in a range of about 20 Å to about 1,000 Å, for example, about 30 Å to about 600 Å. When the thickness of the hole blocking layer is within the range described above, excellent hole blocking characteristics may be obtained without a substantial increase in driving voltage.

The electron transport layer may include BCP, 4,7-diphenyl-1,10-phenanthroline (Bphen), TPBi, tris(8-hydroxyquinolino)aluminum (Alq₃), Balq, 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), or a combination thereof:

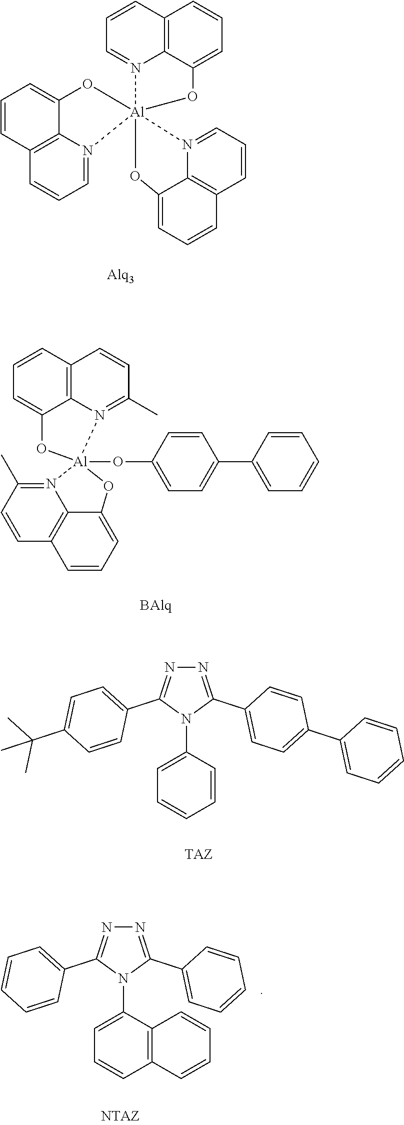

In one or more embodiments, the electron transport layer may include one of Compounds ET1 to ET25 or a combination thereof:

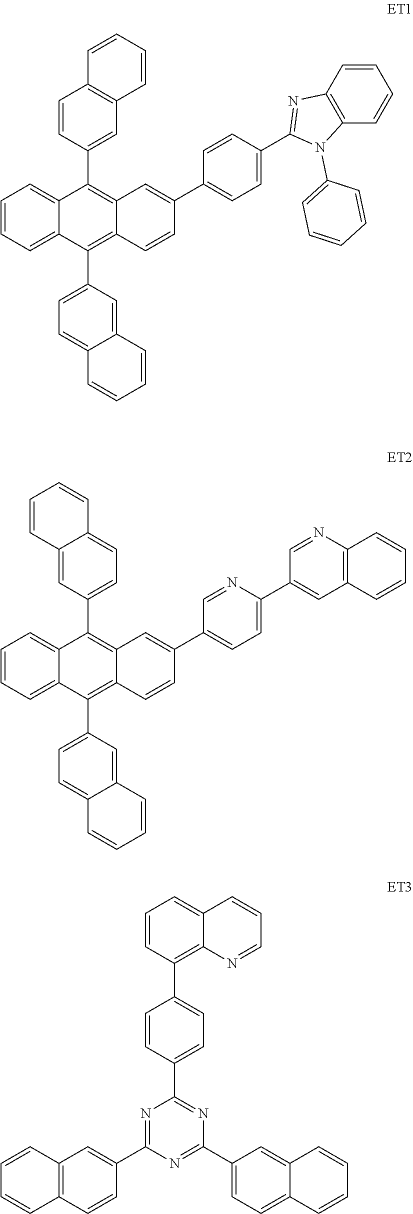 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

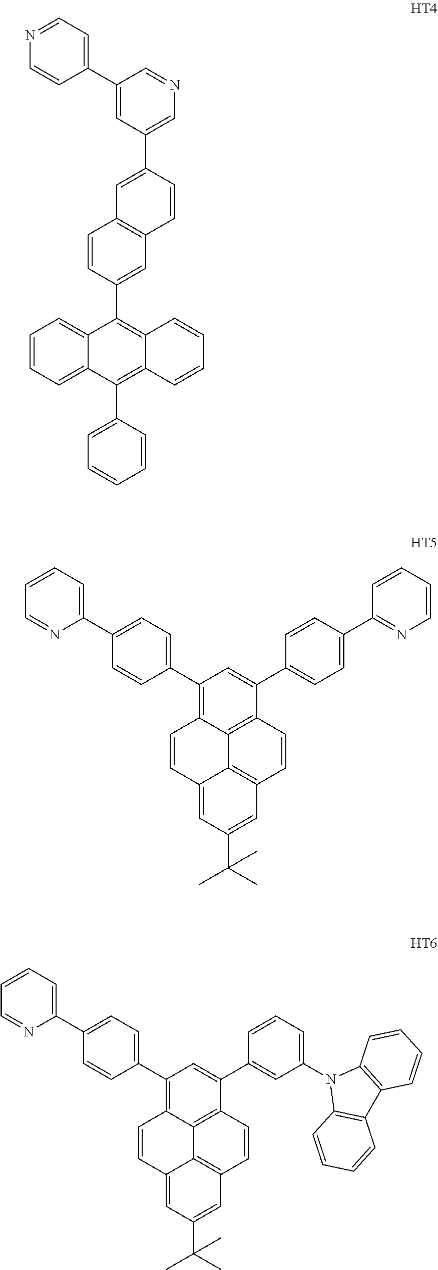 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

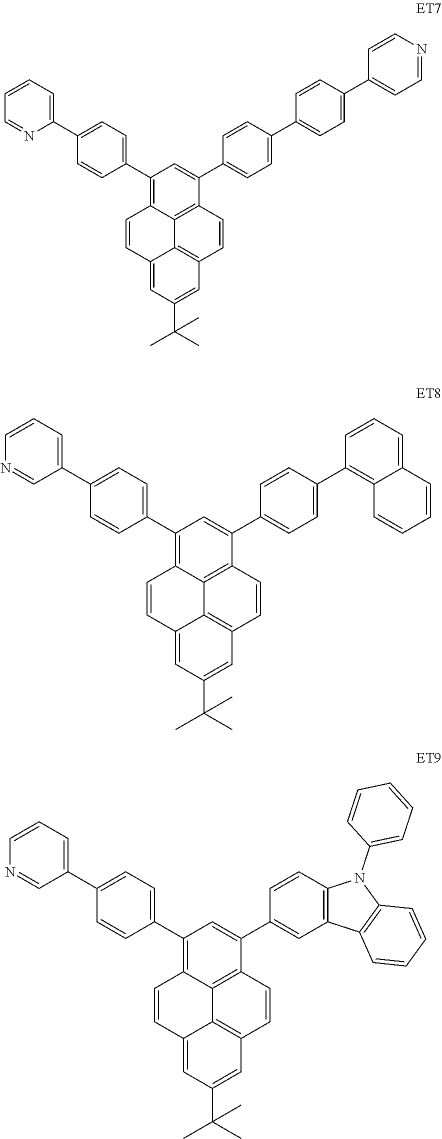 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

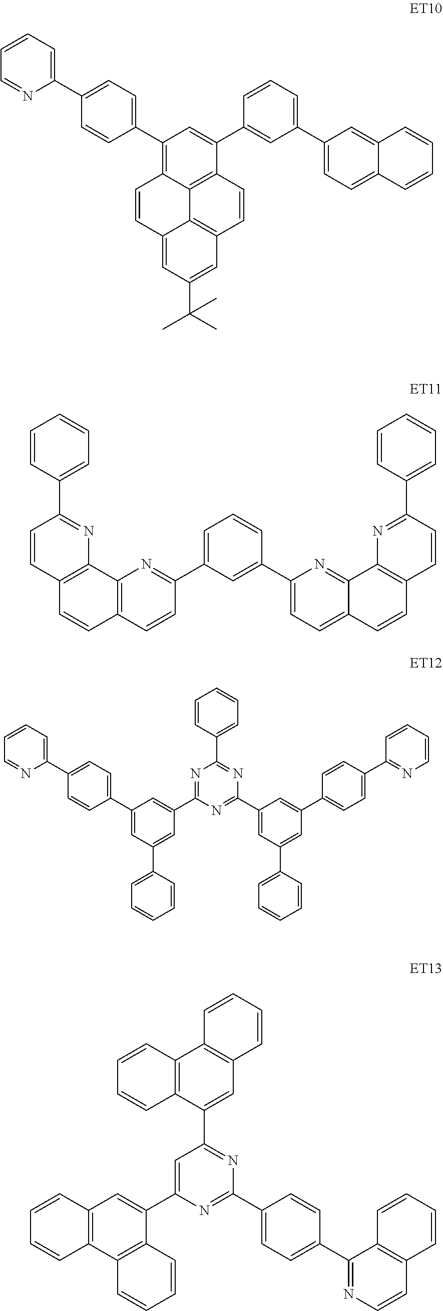 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

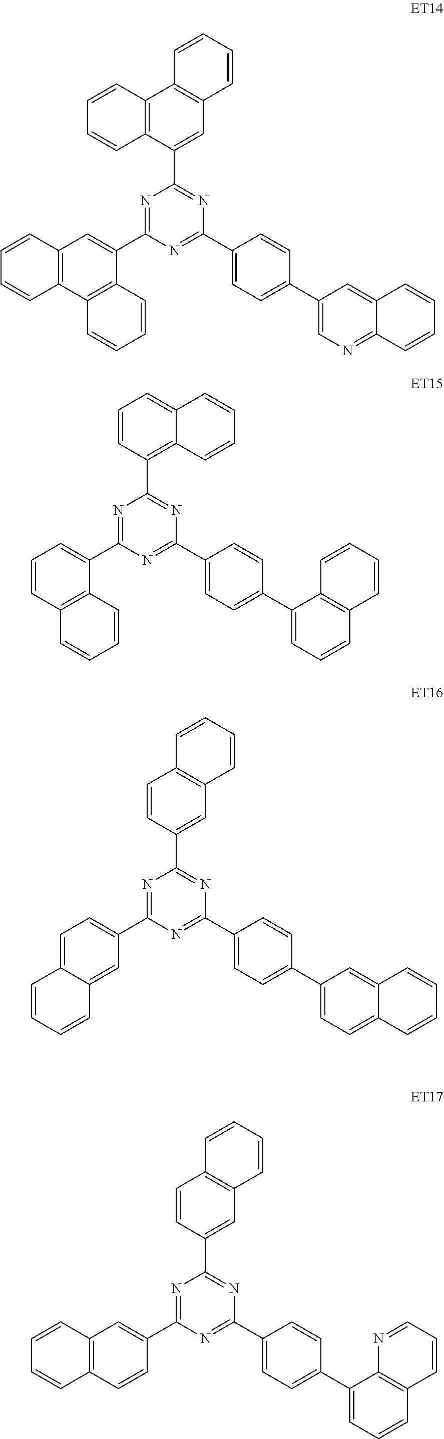 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

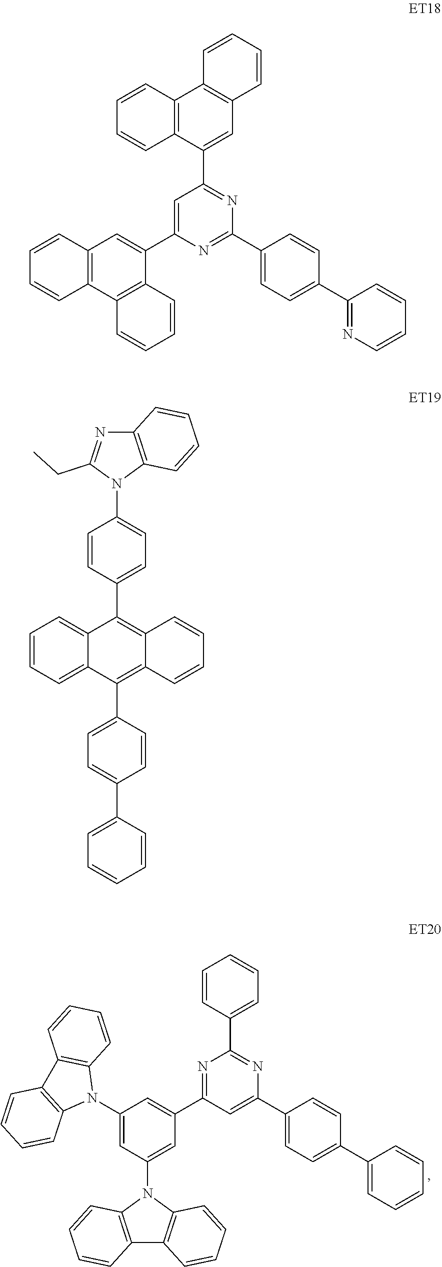 [SMILES: c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

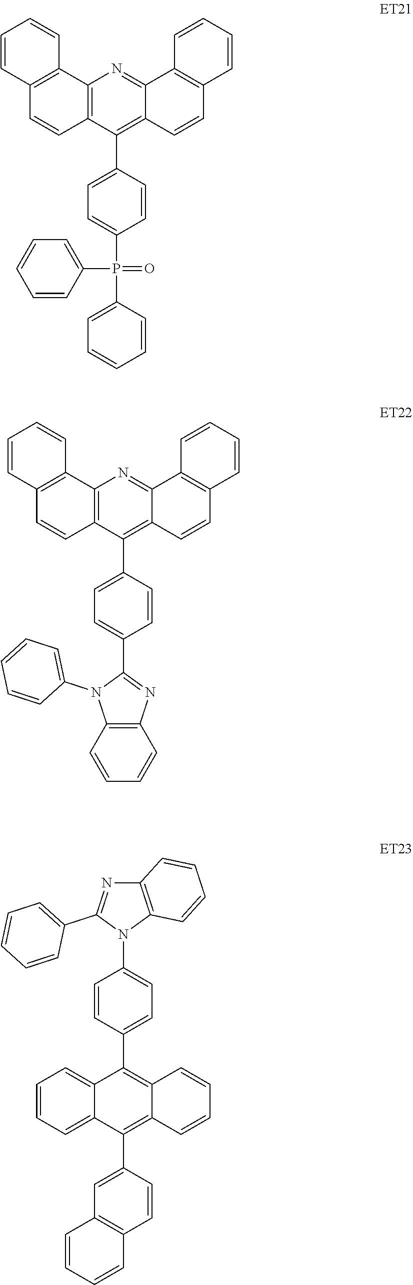 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

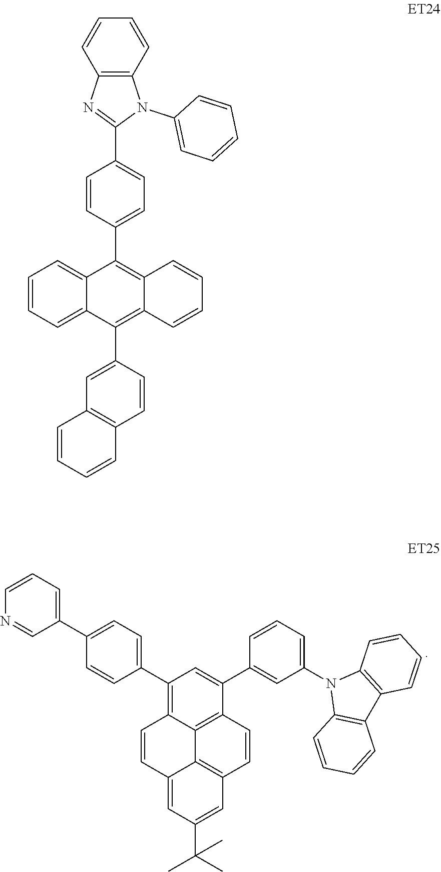 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within the range described above, satisfactory electron transporting characteristics may be obtained without a substantial increase in driving voltage.

The electron transport layer may further include, in addition to the materials as described above, a metal-containing material.

The metal-containing material may include a Li complex. The Li complex may include, for example, Compound ET-D1 or ET-D2:

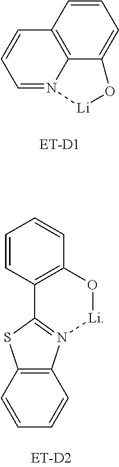

In addition, the electron transport region may include an electron injection layer that facilitates injection of electrons from the second electrode 19.

The electron injection layer may include LiF, NaCl, CsF, Li₂O, BaO, Compound ET-D1, Compound ET-D2, or a combination thereof.

A thickness of the electron injection layer may be in a range of about 1 Å to about 100 Å, for example, about 3 Å to about 90 Å. When the thickness of the electron injection layer is within the range described above, satisfactory electron injection characteristics may be obtained without a substantial increase in driving voltage.

The second electrode 19 may be located on the organic layer 15. The second electrode 19 may be a cathode. A material for forming the second electrode 19 may be a metal, an alloy, an electrically conductive compound, or a combination thereof, each of which has a relatively low work function. For example, lithium (Li), magnesium (Mg), aluminum (Al), silver (Ag), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, a transmissive electrode formed using ITO or IZO may be used as the second electrode 19.

In an embodiment, the composition, the layer including the composition, and the emission layer in the light-emitting device including the composition may not include the following compounds of Group A and 1,3-bis(N-carbazolyl)benzene (mCP):

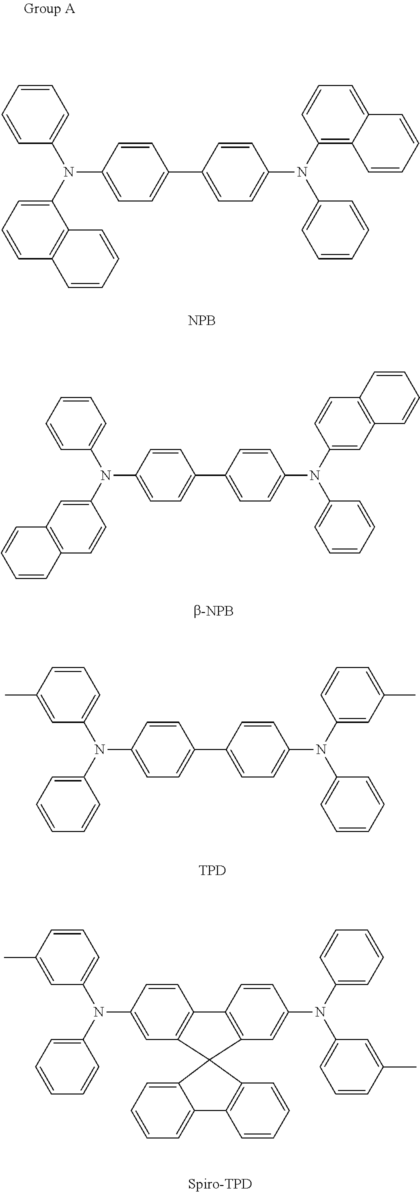

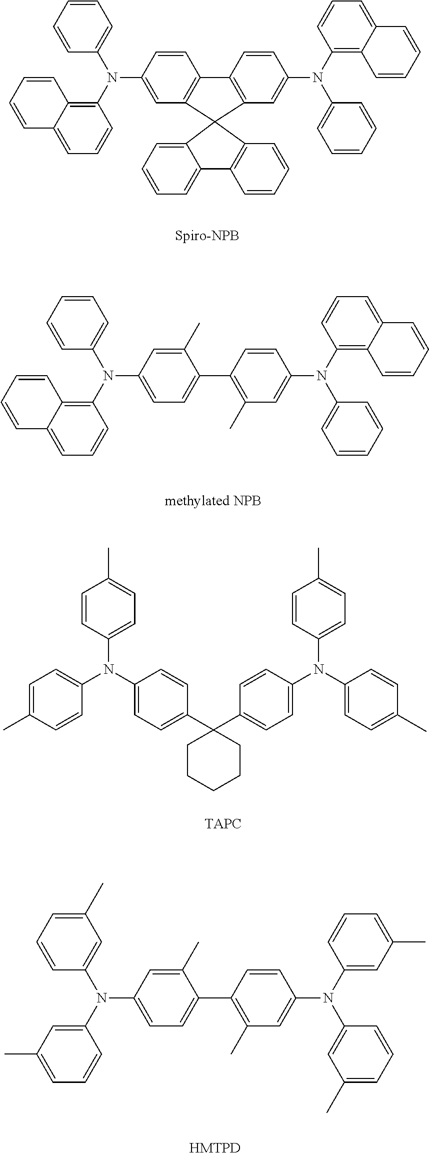

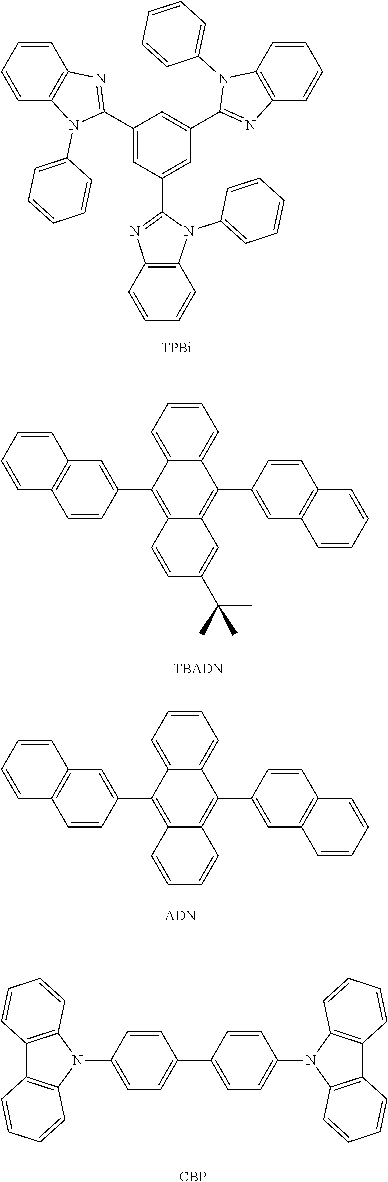

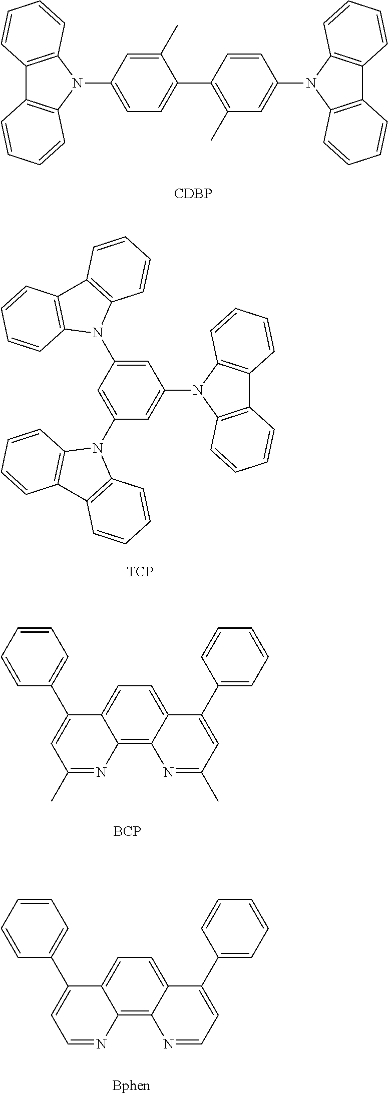

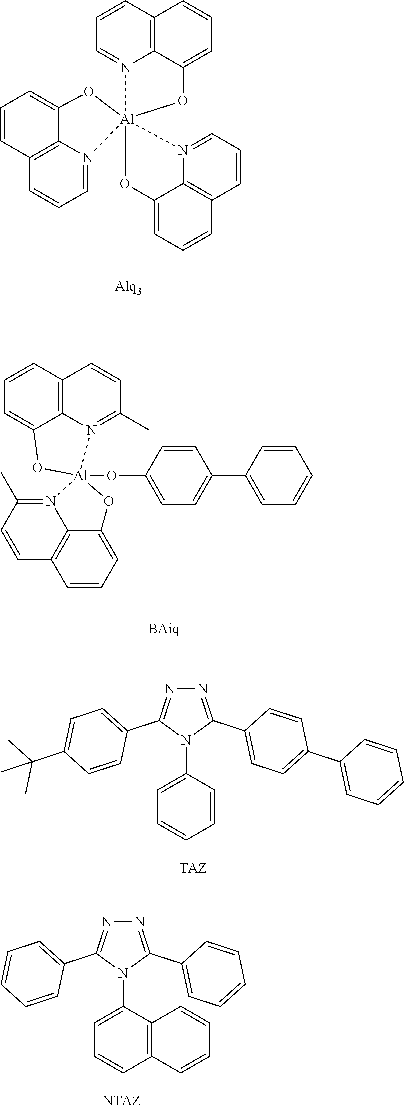

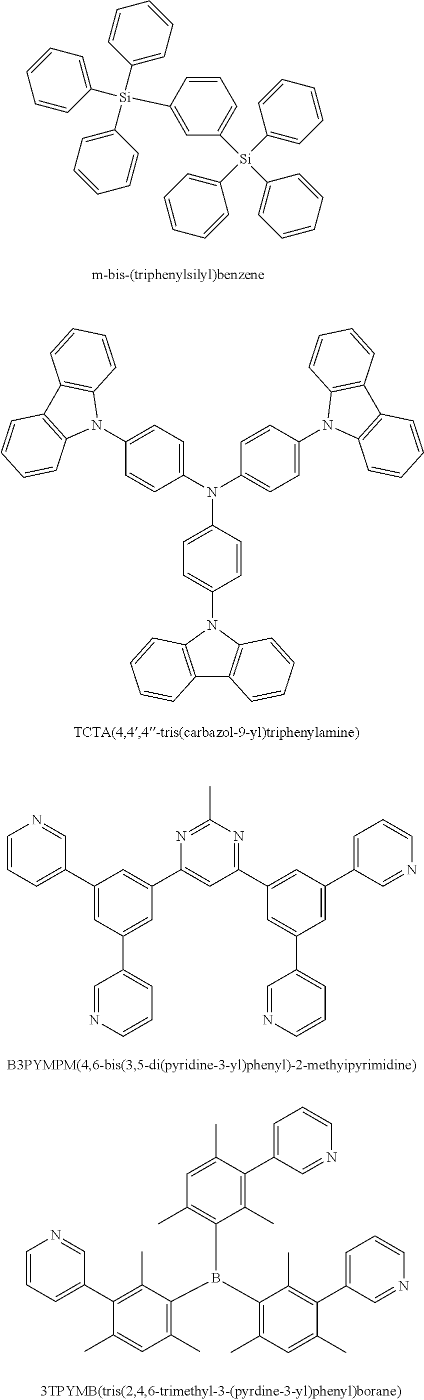 [SMILES: c1ccc([Si](c2ccccc2)(c2ccccc2)c2cccc([Si](c3ccccc3)(c3ccccc3)c3ccccc3)c2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; Cc1nc(-c2cc(-c3cccnc3)cc(-c3cccnc3)c2)cc(-c2cc(-c3cccnc3)cc(-c3cccnc3)c2)n1 ; Cc1cc(C)c(-c2cccnc2)c(C)c1B(c1c(C)cc(C)c(-c2cccnc2)c1C)c1c(C)cc(C)c(-c2cccnc2)c1C]

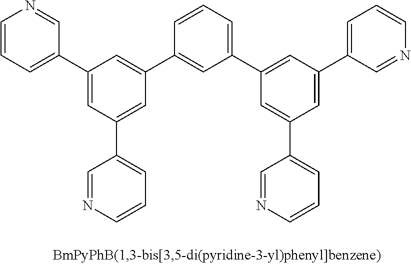 [SMILES: c1cncc(-c2cc(-c3cccnc3)cc(-c3cccc(-c4cc(-c5cccnc5)cc(-c5cccnc5)c4)c3)c2)c1]

Hereinbefore, the organic light-emitting device has been described with reference to the FIGURE, but embodiments of the present disclosure are not limited thereto.

According to another aspect, the organic light-emitting device may be included in an electronic apparatus. Thus, an electronic apparatus including the organic light-emitting device is provided. The electronic apparatus may include, for example, a display, an illumination, a sensor, and the like.

The term “C₁-C₆₀ alkyl group” as used herein refers to a linear or branched saturated aliphatic hydrocarbons monovalent group having 1 to 60 carbon atoms, and the term “C₁-C₆₀ alkylene group, as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. In an embodiment, Formula 9-33 is a branched C₆ alkyl group, for example, a tert-butyl group that is substituted with two methyl groups.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, a propoxy group, a butoxy group, and a pentoxy group.

The term “C₁-C₆₀ alkylthio group” as used herein refers to a monovalent group having the formula of —SA₁₀₁ (wherein A₁₀₁ is the C₁-C₆₀ alkyl group).

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group may include a cyclopropyl group, a cyclobutyl group, a cyclopentyl, cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a saturated cyclic group that includes at least one heteroatom selected from N, O, P, Si, S, Se, Ge, and B as a ring-forming atom and 1 to 10 carbon atoms, and the term “C₁-C₁₀ heterocycloalkylene group” as used herein refers to a divalent group having the same structure as the C₁-C₁₀ heterocycloalkyl group.

Examples of the C₁-C₁₀ heterocycloalkyl group may include a silolanyl group, a silinanyl group, a tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one carbon-carbon double bond in its ring. Examples of the C₁-C₁₀ heterocycloalkenyl group include a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The “C₇-C₆₀ alkyl aryl group” as used herein refers to a C₆-C₆₀ aryl group substituted with at least one C₁-C₆₀ alkyl group. The “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group having at least one heteroatom selected from N, O, P, Si, S, Se, Ge, and B as a ring-forming atom and a cyclic aromatic system having 1 to 60 carbon atoms, and the term “C₁-C₆₀ heteroarylene group” as used herein refers to a divalent group having at least one heteroatom selected from N, O, P, Si, S, Se, Ge, and B as a ring-forming atom and a cyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates —OA₁₀₂ (wherein A₁₀₂ indicates the C₆-C₆₀ aryl group), and the term “C₆-C₆₀ arylthio group” as used herein indicates —SA₁₀₃ (wherein A₁₀₃ indicates the C₆-C₆₀ aryl group).

The term “C₁-C₆₀ heteroaryloxy group” as used herein indicates —OA_{1020′} (wherein A_{102′} indicates the C₁-C₆₀ heteroaryl group), and the term “C₁-C₆₀ heteroarylthio group” as used herein indicates —SA_{103′} (wherein A_{103′} indicates the C₁-C₆₀ heteroaryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, at least one heteroatom selected from N, O, P, Si, S, Se, Ge, and B, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group described above.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Examples of the “C₅-C₃₀ carbocyclic group (unsubstituted or substituted with at least one R₁₀ₐ)” used herein may include an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, S, Se, Ge, and B other than 1 to 30 carbon atoms. The C₁-C₃₀ heterocyclic group may be a monocyclic group or a polycyclic group. The “C₁-C₃₀ heterocyclic group (unsubstituted or substituted with at least one R₁₀ₐ)” may be, for example, a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group (each unsubstituted or substituted with at least one R₁₀ₐ).

In one or more embodiments, examples of the “C₅-C₃₀ carbocyclic group” and “C₁-C₃₀ heterocyclic group” used herein include i) a first ring, ii) a second ring, iii) a condensed ring in which two or more first rings are condensed with each other, iv) a condensed ring in which two or more second rings are condensed with each other, or v) a condensed ring in which at least one first ring and at least one second ring are condensed with each other, the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

The terms “fluorinated C₁-C₆₀ alkyl group (or a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group (—F). In an embodiment, the term “fluorinated C₁ alkyl group (that is, a fluorinated methyl group)” includes —CF₃, —CF₂H, and —CFH₂. The “fluorinated C₁-C₆₀ alkyl group (or, a fluorinated C₁-C₂₀ alkyl group, or the like)”, “the fluorinated C₃-C₁₀ cycloalkyl group”, “the fluorinated C₁-C₁₀ heterocycloalkyl group”, or “the fluorinated a phenyl group” may be i) a fully fluorinated C₁-C₆₀ alkyl group (or, a fully fluorinated C₁-C₂₀ alkyl group, or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, all hydrogen included therein is not substituted with a fluoro group.

The terms “deuterated C₁-C₆₀ alkyl group (or a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one deuterium. In an embodiment, the “deuterated C₁ alkyl group (that is, the deuterated methyl group)” may include —CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, in which, in each group, all hydrogen included therein are not substituted with deuterium.

The term “(C₁-C₂₀ alkyl) ‘X’ group” as used herein refers to a ‘X’ group substituted with at least one C₁-C₂₀ alkyl group. In an embodiment, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of a (C₁ alkyl)phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon selected from ring-forming carbons is substituted with nitrogen.

A substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:

deuterium, —F, —Cl, —Br, —I, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof.

Q₁ to Q₉, Q₁₁ to Q₁₉, Q₂₁ to Q₂₉, and Q₃₁ to Q₃₉ used herein may each independently be: hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, a C₁-C₆₀ alkyl group, a C₆-C₆₀ aryl group, or a combination thereof.

In an embodiment, Q₁ to Q₉, Q₁₁ to Q₁₉, Q₂₁ to Q₂₉, and Q₃₁ to Q₃₉ used herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂, or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

Hereinafter, a compound and an organic light-emitting device according to embodiments are described in detail with reference to Synthesis Examples and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1 (Synthesis of Compound GD-1)

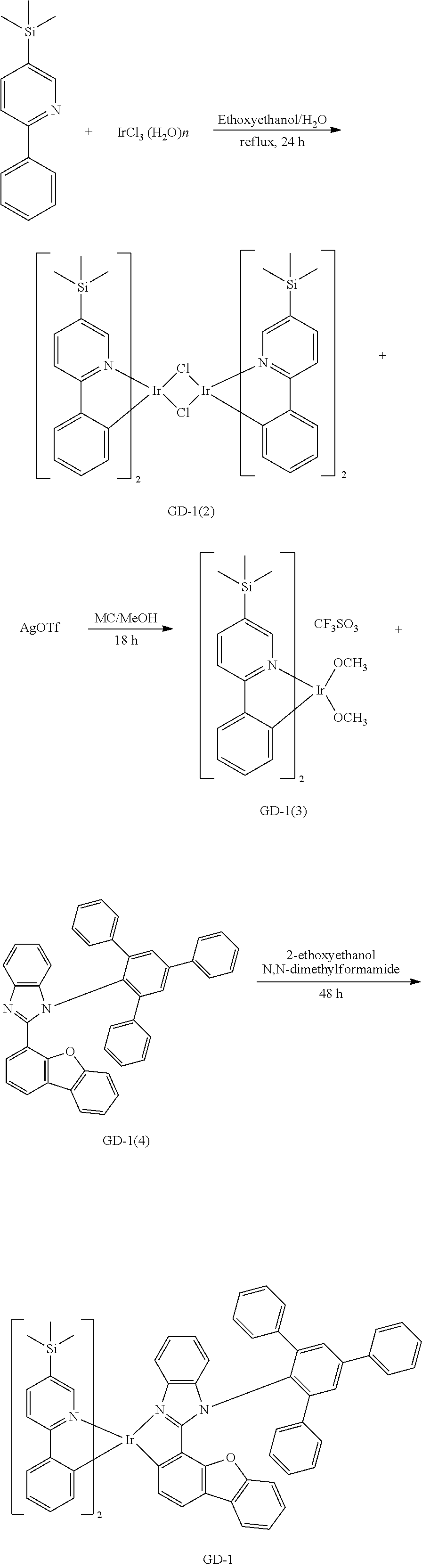

### Synthesis of Compound GD-1(2)

2-phenyl-5-(trimethylsilyl)pyridine (4.21 grams (g), 18.5 millimoles (mmol)) and iridium chloride hydrate (IrCl₃(H₂O)ₙ, n=3) (2.96 g, 8.40 mmol) were mixed with 30 milliliters (mL) of 2-ethoxyethanol and 10 mL of deionized (DI) water and then stirred under reflux for 24 hours, and then, the temperature was lowered to room temperature. The resulting solid was separated by filtration, washed sufficiently with water, methanol, and hexane, in this stated order, and then dried in a vacuum oven to obtain 5.22 g (yield of 87%) of Compound GD-1(2).

### Synthesis of Compound GD-1(3)

Compound GD-1(2) (2.28 g, 1.68 mmol) was mixed with 60 mL of methylene chloride (MC), and then, silver trifluoromethanesulfonate (AgOTf) (0.86 g, 3.36 mmol) was added thereto after being mixed with 20 mL of methanol (MeOH). Thereafter, the mixture was stirred for 18 hours at room temperature while light was blocked with aluminum foil, and then filtered through Celite to remove the resulting solid, and the filtrate was subjected to reduced pressure to obtain a resultant (Compound GD-1(3)), which was used in the next reaction without an additional purification process.

### Synthesis of Compound GD-1

Compound GD-1(3) (2.66 g, 2.98 mmol) and Compound GD-1(4) (2-(dibenzo[b,d]furan-4-yl)-1-(5′-phenyl-[1,1′:3′,1″-terphenyl]-4′-yl)-1H-benzo[d]imidazole) (1.79 g, 2.99 mmol) were mixed with 30 mL of 2-ethoxyethanol and 30 mL of N,N-dimethylformamide and then stirred under reflux for 48 hours, and then, the temperature was lowered to room temperature. The obtained mixture was subjected to reduced pressure to obtain a solid, on which column chromatography (eluent: ethyl acetate (EA) and hexanes) was performed to obtain 1.12 g (yield of 30%) of Compound GD-1.

High resolution mass spectrometry (HRMS) using matrix assisted laser desorption ionization (MALDI) (HRMS (MALDI)) calcd for C₇₁H₅₉IrN₄OSi₂: m/z 1234.66 Found: 1234.66.

### Synthesis Example 2 (Synthesis of Compound GD-2)

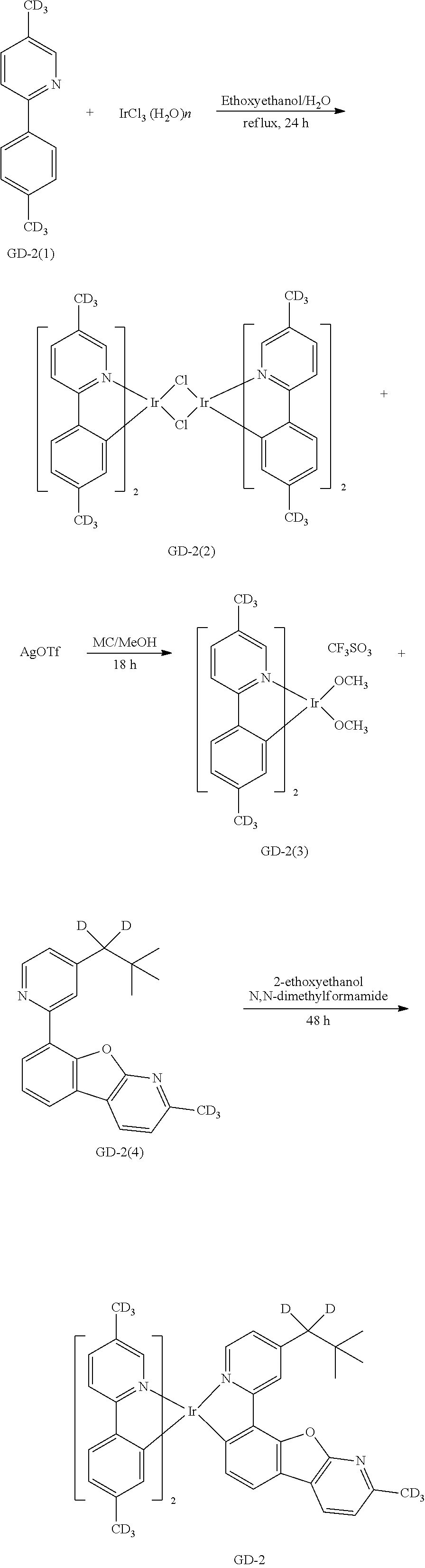

### Synthesis of Compound GD-2(2)

4.30 g (yield of 82%) of Compound GD-2(2) was obtained in a similar manner as used to obtain Compound GD-1(2) of Synthesis Example 1, except that Compound GD-2(1) (5-(methyl-d3)-2-(p-tolyl-d3)pyridine) was used instead of 2-phenyl-5-(trimethylsilyl)pyridine.

### Synthesis of Compound GD-2(3)

Compound GD-2(3) was obtained in a similar manner as used to obtain Compound GD-1(3) of Synthesis Example 1, except that Compound GD-2(2) was used instead of Compound GD-1(2). Compound GD-2(3) obtained was used in the next reaction without an additional purification process.

### Synthesis of Compound GD-2

1.45 g (yield of 39%) of Compound GD-2 was obtained in a similar manner as used to obtain Compound GD-1 of Synthesis Example 1, except that Compound GD-2(3) was used instead of Compound GD-1(3), and Compound GD-2(4) was used instead of Compound GD-1(4).

HRMS (MALDI) calcd for C₄₈H₂₈D₁₇IrN₄O: m/z 904.43 Found: 904.43.

### Synthesis Example 3 (Synthesis of Compound RD-1)

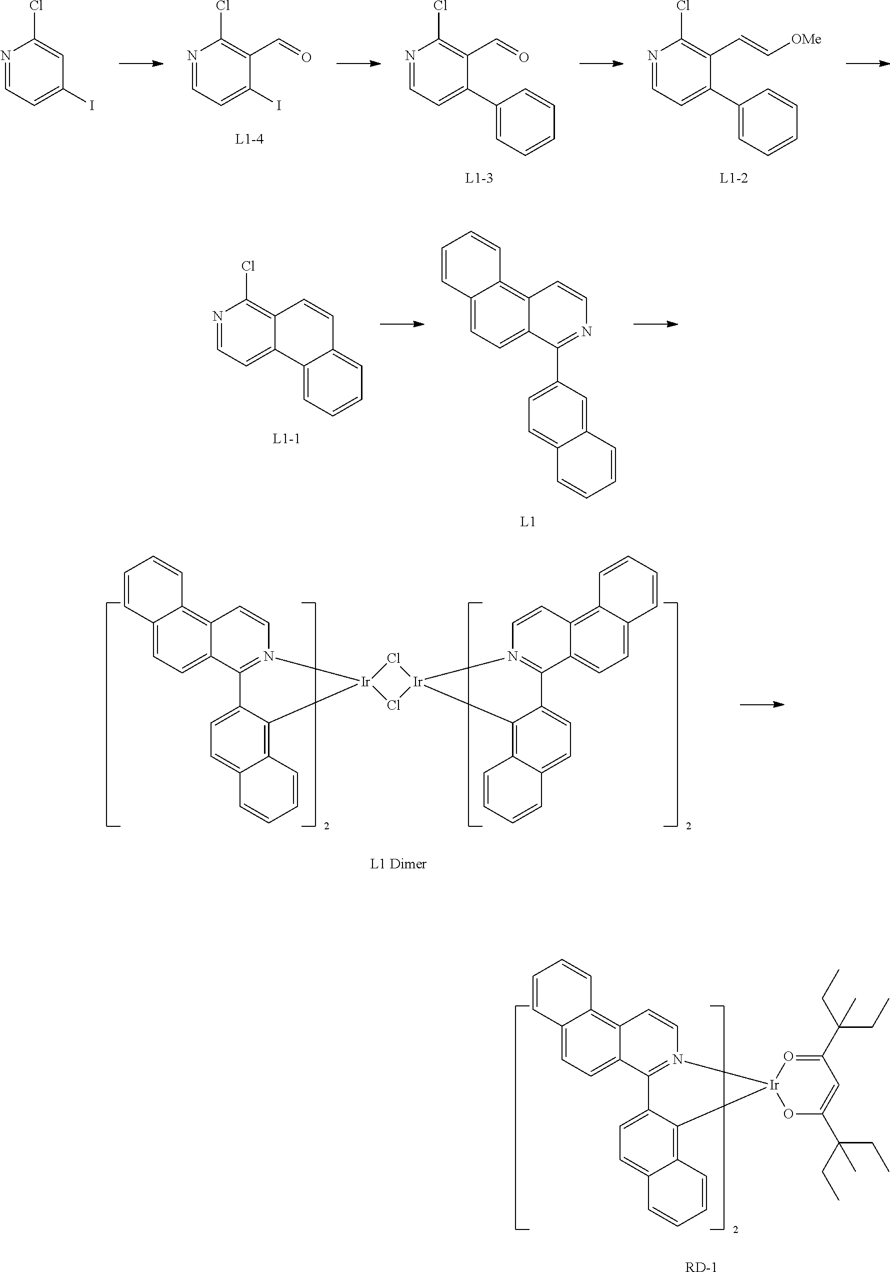

### Synthesis of Intermediate L1-4

5 g (20.9 mmol) of 2-chloro-4-iodopyridine was dissolved in 50 mL of anhydrous THF, and then, 12.5 mL (25 mmol) of 2.0 M lithium diisopropylamide (in THF) was slowly added dropwise thereto at a temperature of −78° C. After about 3 hours, 2.5 mL (32 mmol) of ethyl formate was slowly added dropwise thereto, followed by stirring at room temperature for 18 hours. When the reaction was completed, water and ethyl acetate were added to the reaction mixture and an extraction process was performed thereon, and the obtained organic layer was dried using magnesium sulfate and distilled under reduced pressure. The resultant was purified by liquid chromatography to obtain Intermediate L1-4.

### Synthesis of Intermediate L1-3

1.9 g (7.2 mmol) of Intermediate L1-4 was dissolved in 60 mL of acetonitrile and 15 mL of water, and then, 0.4 g (0.5 mmol) of PdCl₂(PPh₃)₂, 7.2 mmol of phenylboronic acid, and 2.5 g (18.0 mmol) of K₂CO₃ were added thereto, followed by refluxing while heating at a temperature of 80° C. for 18 hours. When the reaction was completed, the reaction mixture was concentrated under reduced pressure, dichloromethane and water were added thereto, followed by extraction, and the obtained organic layer was dried using magnesium sulfate and distilled under reduced pressure. The resultant was purified by liquid chromatography to obtain Intermediate L1-3.

### Synthesis of Intermediate L1-2

5.4 g (15.8 mmol) of (methoxymethyl)triphenylphosphonium chloride was dissolved in 50 mL of anhydrous ethyl ether, and then, 16 mL of 1.0 M potassium tert-butoxide solution was added dropwise thereto. After stirring at room temperature for about 1 hour, 1.5 g (6.3 mmol) of Intermediate L1-3 dissolved in 30 mL of anhydrous THF was slowly added dropwise thereto, followed by stirring at room temperature for 18 hours. When the reaction was completed, water and ethyl acetate were added to the reaction mixture and an extraction process was performed thereon, and the obtained organic layer was dried using magnesium sulfate and distilled under reduced pressure. The resultant was purified by liquid chromatography to obtain Intermediate L1-2.

### Synthesis of Intermediate 1-1

1.4 g (5.1 mmol) of Intermediate L1-2 was dissolved in 40 mL of dichloromethane, and 3.0 mL of methanesulfonic acid was slowly added dropwise thereto, followed by stirring at room temperature for about 18 hours. After the reaction was completed, an extraction process was performed thereon after adding a saturated aqueous hydrogen carbonate solution thereto, and the obtained organic layer was dried using magnesium sulfate and distilled under reduced pressure. The resultant was purified by liquid chromatography to obtain Intermediate L1-1.

### Synthesis of Intermediate L1

1.0 g (4.1 mmol) of Intermediate 1-1 was dissolved in 40 mL of THF and 10 mL of water, and then, 1.6 g (6.2 mmol) of 4,4,5,5-tetramethyl-2-(naphthalen-2-yl)-1,3,2-dioxaborolane, 0.09 g (0.4 mmol) of palladium acetate (Pd(OAc)₂), 0.35 g (0.82 mmol) of Sphos, and 1.4 g (10.3 mmol) of K₂CO₃ were added thereto, followed by refluxing while heating for one day. After the reaction was completed, an extraction process was performed thereon after adding ethyl acetate and water thereto, and the obtained organic layer was dried using magnesium sulfate and distilled under reduced pressure. The resultant was purified by liquid chromatography to obtain Intermediate L1.

### Synthesis of Intermediate L1 Dimer

1.05 g (3.4 mmol) of Intermediate L1 and 0.6 g (1.6 mmol) of iridium chloride were mixed with 40 mL of ethoxyethanol and 15 mL of distilled water, followed by refluxing while heating for 24 hours. After the reaction was completed, the temperature was lowered to room temperature, and the solid produced therefrom was filtered and washed sufficiently in the order of water/methanol/hexane. The obtained solid was dried in a vacuum oven to obtain Intermediate L1 Dimer.

### Synthesis of Compound RD-1

Intermediate L1 Dimer (0.63 mmol), 0.9 g (4.5 mmol) of 3,7-diethyl-3,7-dimethylnonane-4,6-dione, and 0.48 g (4.5 mmol) of Na₂CO₃ were mixed with 40 mL of ethoxyethanol and then stirred at a temperature of 90° C. for 24 hours to proceed a reaction. After the reaction was completed, the temperature was lowered to room temperature, and the solid produced therefrom was filtered and purified by liquid chromatography to obtain 0.008 g (yield of 30%) of Compound RD-1.

Liquid chromatography-mass spectrometry (LC-MS) m/z=1042.40 (M+H)⁺.

### Evaluation Example 1

On a quartz substrate, compounds shown in Table 1 were vacuum-deposited at a vacuum pressure of 10⁻⁷ torr at a weight ratio shown in Table 1 to manufacture Films G-1, G-2, G-1C, G-2C, R-1, R-2, R-1C, R-2C, R-1 D, and R-2D each having a thickness of 40 nm.

Subsequently, the photoluminescence emission peak wavelength (λₘₐₓ, nm) and photoluminescence quantum yield (PLQY, %) of each of Films G-1, G-2, G-1C, G-2C, R-1, R-2, R-1C, R-2C, R-1 D, and R-2D was measured using a Quantaurus-QY Absolute PL quantum yield spectrometer (equipped with a xenon light source, a monochromator, a photonic multichannel analyzer, and an integrating sphere, and using PLQY measurement software (manufactured by Hamamatsu Photonics, Ltd., Shizuoka, Japan)). In the measurement, the excitation wavelength was scanned at intervals of 10 nm from 320 nm to 380 nm, and a spectrum measured at the excitation wavelength of 320 nm among the scanned wavelengths was adopted. Accordingly, the photoluminescence emission wavelength (λₘₐₓ) and photoluminescence quantum yield (PLQY) of each of Compounds GD-1, GD-2, GD-1C, GD-2C, RD-1, RD-2, RD-1C, RD-2C, RD-1 D, and RD-2D included in Films G-1, G-2, G-1C, G-2C, R-1, R-2, R-1C, R-2C, R-1 D, and R-2D were evaluated, and the results are shown in Tables 2 and 3.

TABLE 1

| | Film |
|---|---|
| | composition |
| | (weight |
| Film no. | ratio) |
| G-1 | H-H1:H- |
| | H2:GD-1 |
| | (47.5:47.5:5) |
| G-2 | H-H1:H- |
| | H2:GD-2 |
| | (47.5:47.5:5) |
| G-1C | H-H1:H- |
| | H2:GD-1C |
| | (47.5:47.5:5) |
| G-2C | H-H1:H- |
| | H2:GD-2C |
| | (47.5:47.5:5) |
| R-1 | H52:RD-1 |
| | (98:2) |
| R-2 | H52:RD-2 |
| | (98:2) |
| R-1C | H52:RD-1C |
| | (98:2) |
| R-2C | H52:RD-2C |
| | (98:2) |
| R-1D | H52:RD-1D |
| | (98:2) |
| R-2D | H52:RD-2D |
| | (98:2) |
| 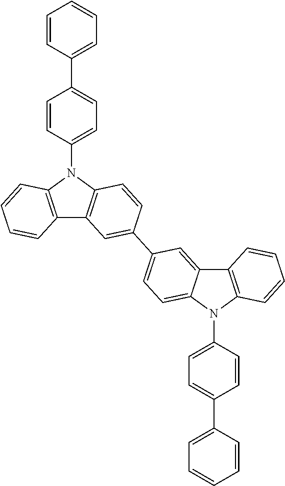 [SMILES: c1ccc(-c2ccc(-n3c4ccccc4c4cc(-c5ccc6c(c5)c5ccccc5n6-c5ccc(-c6ccccc6)cc5)ccc43)cc2)cc1] | H-H1 |
| 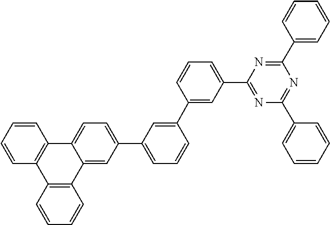 [SMILES: c1ccc(-c2nc(-c3ccccc3)nc(-c3cccc(-c4cccc(-c5ccc6c7ccccc7c7ccccc7c6c5)c4)c3)n2)cc1] | H-H2 |
| 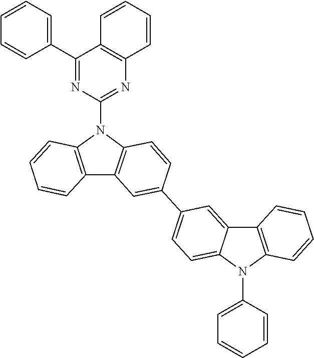 [SMILES: c1ccc(-c2nc(-n3c4ccccc4c4cc(-c5ccc6c(c5)c5ccccc5n6-c5ccccc5)ccc43)nc3ccccc23)cc1] | H52 |

### Evaluation Example 2

The photoluminescence spectrum of each of Films G-1, G-2, G-1C, G-2C, R-1, R-2, R-1C, R-2C, R-1D, and R-2D was evaluated at room temperature by using TRPL measurement system FluoTime 300 manufactured by PicoQuant and a pumping source PLS340 manufactured by PicoQuant (excitation wavelength=340 nm, spectral width=20 nm), and then, the wavelength of main peak of the spectrum was determined. PLS340 repeated the measure of the number of photons emitted from each film at the main peak by a photon pulse (pulse width=500 picoseconds) applied to each film according to the time, based on time-correlated single photon counting (TCSPC), thereby obtaining a sufficiently fittable TRPL curve. One or more exponential decay functions were fitted to the result obtained therefrom, thereby obtaining T_{decay}(Ex), that is, decay time, of each of Films G-1, G-2, G-1C, G-2C, R-1, R-2, R-1C, R-2C, R-1 D, and R-2D, and radiative decay rates calculated therefrom are shown in Tables 2 and 3. A function for fitting is as shown in Equation 20, and from among T_{decay} values obtained from each exponential decay function used for fitting, the largest T_{decay} was obtained as T_{decay} (Ex). In this regard, the same measurement was performed during the same measurement time as that for obtaining TRPL curve in the dark state (in which pumping signals entering a film are blocked) to obtain a baseline or a background signal curve for use as a baseline for fitting.

$$f ( t ) = {\sum }_{i = 1}^{n} {A}_{i} exp ( - t / {T}_{decay , i} ) \qquad Equation 20$$

Evaluation Example 3

The photoluminescence (emission intensity) at each angle of each of Films G-1, G-2, G-1C, G-2C, R-1, R-2, R-1C, R-2C, R-1D, and R-2D was measured from −150° to +150° by using Luxol-OLED/analyzer LOA-100 manufactured by CoCoLink Inc., and then, the horizontal orientation ratio of each of Compounds GD-1, GD-2, GD-1C, GD-2C, RD-1, RD-2, RD-1C, RD-2C, RD-1 D, and RD-2D were calculated by using a fitting program of the analyzer, and the results are shown in Tables 2 and 3.

### Evaluation Example 4

The HOMO energy levels of Compounds GD-1, GD-2, GD-1C, GD-2C, RD-1, RD-2, RD-1C, RD-2C, RD-1D, and RD-2D were evaluated by using a photoelectron spectrometer (manufactured by RIKEN KEIKI Co., Ltd.: AC3) under atmospheric pressure, and the results are shown in Tables 2 and 3.

TABLE 2

| Com- | | | Radiative | Horizontal | |
|---|---|---|---|---|---|
| pound | λₘₐₓ | PLQY | decay rate | orientation | HOMO |
| No. | (nm) | (%) | (s⁻¹) | ratio (%) | (eV) |
| GD-1 | 530 | 91.4% | 8.35 × 10⁵ | 88% | −5.34 |
| GD-2 | 525 | 91.2% | 7.31 × 10⁵ | 77% | −5.25 |
| GD-1C | 516 | 79.1% | 8.64 × 10⁵ | 67% | −5.35 |
| GD-2C | 433 | 50.2% | 2.50 × 10⁵ | 68% | −5.51 |

| | |
|---|---|
| 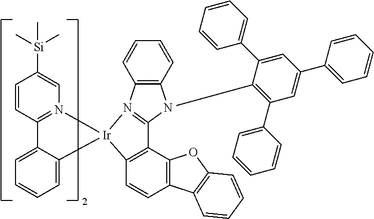 | GD-1 |
| 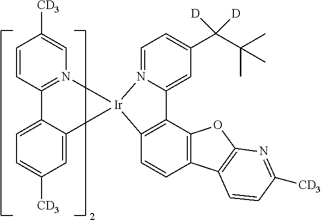 | GD-2 |
| 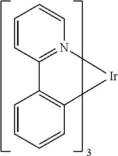 | GD-1C |
| 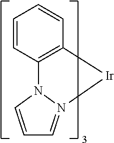 | GD-2C |

TABLE 3

| Com- | | | Radiative | Horizontal | |
|---|---|---|---|---|---|
| pound | λₘₐₓ | PLQY | decay rate | orientation | HOMO |
| No. | (nm) | (%) | (s⁻¹) | ratio (%) | (eV) |
| RD-1 | 634 | 70% | 6.03 × 10⁵ | 90% | −5.37 |
| RD-2 | 618 | 56% | 5.61 × 10⁵ | 86% | −5.35 |
| RD-1C | 618 | 72.7% | 6.61 × 10⁵ | 79% | −5.39 |
| RD-2C | 520 | 70.5% | 5.56 × 10⁵ | 71% | −5.41 |
| RD-1D | 592 | 69.2% | 6.71 × 10⁵ | 77% | −5.48 |
| RD-2D | 584 | 65.4% | 5.59 × 10⁵ | 78% | −5.51 |

| | |
|---|---|
| 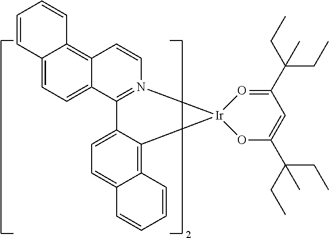 | RD-1 |
| 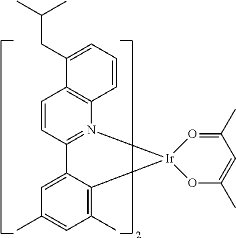 | RD-2 |
| 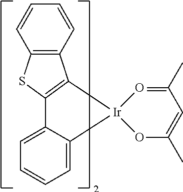 | RD-1C |
| 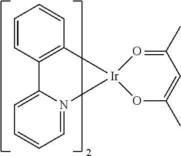 | RD-2C |
| 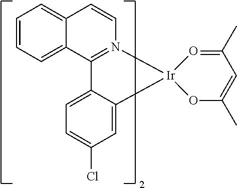 | RD-1D |
| 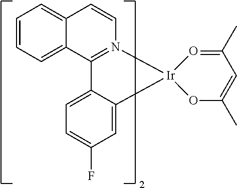 | RD-2D |

### Manufacture of OLED G-1

An ITO (as an anode)-patterned glass substrate was cut to a size of 50 mm×50 mm×0.5 mm, sonicated with isopropyl alcohol and pure water, each for 5 minutes, and then cleaned by exposure to ultraviolet rays and ozone for 30 minutes. The resultant glass substrate was loaded onto a vacuum deposition apparatus.

HT3 and F6-TCNNQ were vacuum-deposited on the anode at a weight ratio of 98:2 to form a hole injection layer having a thickness of 100 Å, and then, HT3 was vacuum-deposited on the hole injection layer to form a hole transport layer having a thickness of 1,350 Å. H-H1 was vacuum-deposited on the hole transport layer to form an electron blocking layer having a thickness of 300 Å.

Subsequently, a host and a dopant were co-deposited at the weight ratio shown in Table 4 on the electron blocking layer to form an emission layer having a thickness of 400 Å. As the host, H-H1 and H-H2 were used at a weight ratio of 5:5, and as the dopant, the first compound and the second compound shown in Table 4 were used at a weight ratio of 1:1.

Thereafter, ET3 and ET-D1 were co-deposited at a volume ratio of 50:50 on the emission layer to form an electron transport layer having a thickness of 350 Å, ET-D1 was vacuum-deposited on the electron transport layer to form an electron injection layer having a thickness of 10 Å, and Al was vacuum-deposited on the electron injection layer to form a cathode having a thickness of 1,000 Å, thereby completing the manufacture of OLED G-1.

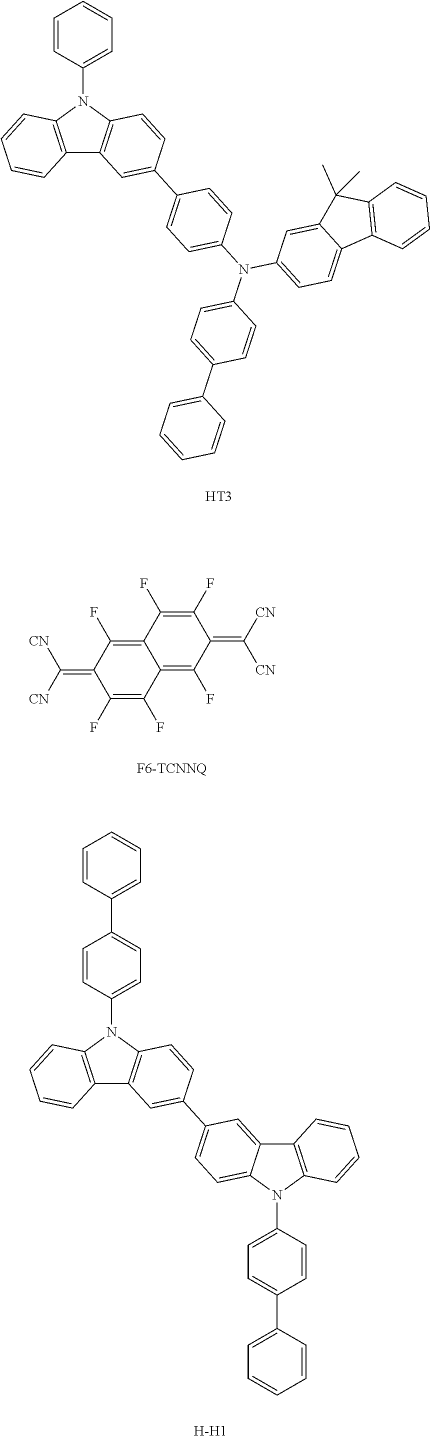

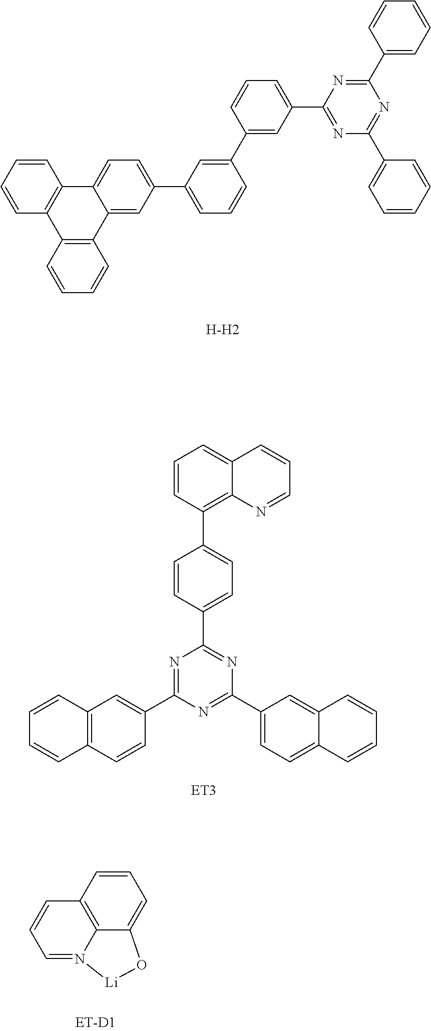

### Manufacture of OLEDs G-A to G-C

OLEDs G-A to G-C were manufactured in a similar manner as used to manufacture OLED G-1, except that, in forming an emission layer, for use as a dopant, corresponding compounds shown in Table 4 were used instead of the first compound and the second compound of OLED G-1.

### Evaluation Example 5

The driving voltage (V), emission peak wavelength λₘₐₓ (nm), maximum value of external quantum efficiency (Max EQE, %), and lifespan (LT₉₇, hr) of each of OLEDs G-1 and G-A to G-C were evaluated, and the results are shown in Table 4. A current-voltage meter (Keithley 2400) and a luminance meter (Minolta Cs-1000A) were used as an apparatus for evaluation, and the lifespan (T₉₇, relative % at 16,000 candela per square meter (cd/m²) or nit) were obtained by measuring the amount of time (hours, hr) that elapsed until luminance was reduced to 97% of the initial luminance of 100%, and the results are expressed as a relative value (%).

TABLE 4

| | | | Weight | | | | |
|---|---|---|---|---|---|---|---|
| | | | ratio of | | | Max | |
| | | | host to | | | EQE | LT₉₇ |
| | Dopant in emission | | dopant | | | (rela- | (rela- |
| | layer | | in | Driving | | tive | tive |
| | First | Second | emission | voltage | λₘₐₓ | value, | value, |
| | compound | compound | layer | (V) | (nm) | %) | %) |
| OLED | GD-1 | GD-2 | 90:10 | 4.30 | 530 | 98 | 140 |
| G-1 | | | | | | | |
| OLED | GD-1 | | 95:5 | 4.29 | 530 | 100 | 100 |
| G-A | | | | | | | |
| OLED | GD-2 | | 95:5 | 4.36 | 525 | 89 | 25 |
| G-B | | | | | | | |
| OLED | GD-1C | GD-2C | 90:10 | 5.4 | 516 | 42 | <10 |
| G-C | | | | | | | |

| | |
|---|---|
| 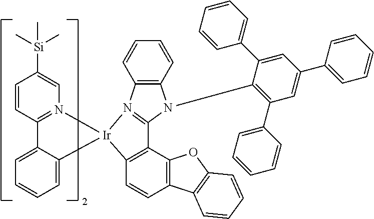 | GD-1 |
| 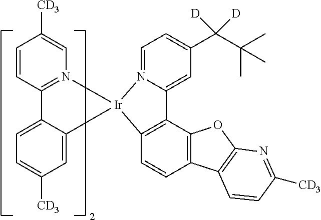 | GD-2 |
| 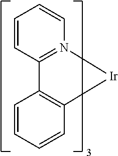 | GD-1C |
| 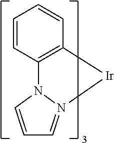 | GD-2C |

Referring to Table 4, it was confirmed that OLED G-1 emitted green light and, as compared with each of OLEDs G-A to G-C, had an improved or equivalent driving voltage, improved or equivalent external quantum efficiency, and improved lifespan characteristics.

### Manufacture of OLED R-1

As an anode, an ITO-patterned glass substrate was cut to a size of 50 mm×50 mm×0.5 mm, sonicated with isopropyl alcohol, and pure water each for 5 minutes, and then cleaned by exposure to ultraviolet rays and ozone for 30 minutes. Then, the ITO-patterned glass substrate was provided to a vacuum deposition apparatus.

HT3 and F6-TCNNQ were co-deposited by vacuum on the ITO anode at a weight ratio of 98:2 to form a hole injection layer having a thickness of 100 Å, and HT3 was vacuum-deposited on the hole injection layer to form a hole transport layer having a thickness of 1,350 Å, and then, HT21 was vacuum-deposited on the hole transport layer to form an electron blocking layer having a thickness of 300 Å.

Subsequently, a host and a dopant were co-deposited at the weight ratio shown in Table 5 on the electron blocking layer to form an emission layer having a thickness of 400 Å. H52 was used as the host, and as the dopant, the first compound and the second compound shown in Table 5 were used at a weight ratio of 1:1.

Thereafter, ET3 and ET-D1 were co-deposited at a volume ratio of 50:50 on the emission layer to form an electron transport layer having a thickness of 350 Å, ET-D1 was vacuum-deposited on the electron transport layer to form an electron injection layer having a thickness of 10 Å, and Al was vacuum-deposited on the electron injection layer to form a cathode having a thickness of 1,000 Å, thereby completing the manufacture of OLED R-1.

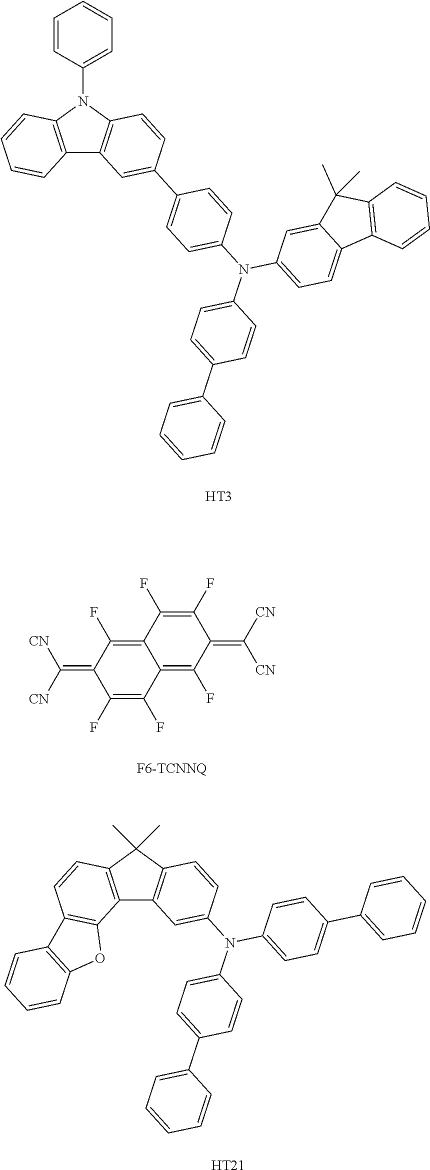

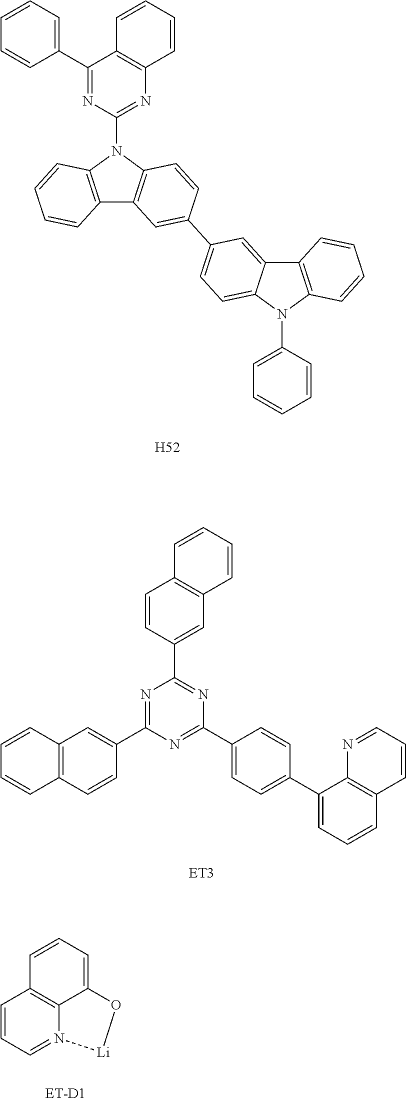

### Manufacture of OLEDs R-A to R-D

OLEDs R-A to R-D were manufactured in a similar manner as used to manufacture OLED R-1, except that, in forming an emission layer, for use as a dopant, corresponding compounds shown in Table 5 were used instead of the first compound and the second compound of OLED R-1.

### Evaluation Example 6

The driving voltage (V), emission peak wavelength λₘₐₓ (nm), maximum value of external quantum efficiency (Max EQE, relative %), and lifespan (LT₉₇, hr) of each of OLEDs R-1 and R-A to R-D were evaluated, and the results are shown in Table 5. A current-voltage meter (Keithley 2400) and a luminance meter (Minolta Cs-1000A) were used as an apparatus for evaluation, and the lifespan (T₉₇, relative % at 7,000 cd/m² or nit) were obtained by measuring the amount of time (hr) that elapsed until luminance was reduced to 97% of the initial luminance of 100%, and the results are expressed as a relative value (%).

TABLE 5

| | | | Weight | | | | |
|---|---|---|---|---|---|---|---|
| | | | ratio of | | | | |
| | | | host to | | | | LT₉₇ |
| | Dopant in emission | | dopant | | | | (rela- |
| | layer | | in | Driving | | Max | tive |
| | First | Second | emission | voltage | λmax | EQE | value, |
| | compound | compound | layer | (V) | (nm) | (%) | %) |
| OLED | RD-1 | RD-2 | 98:2 | 3.10 | 631 | 104 | 141 |
| R-1 | | | | | | | |
| OLED | RD-1 | | 98::2 | 3.09 | 634 | 100 | 100 |
| R-A | | | | | | | |
| OLED | RD-2 | | 98:2 | 3.13 | 618 | 99 | 117 |
| R-B | | | | | | | |
| OLED | RD-1C | RD-2C | 98:2 | 3.03 | 618 | 82 | <10 |
| R-C | | | | | | | |
| OLED | RD-1D | RD-2D | 98:2 | 3.01 | 592 | 85 | <10 |
| R-D | | | | | | | |

| | |
|---|---|
| 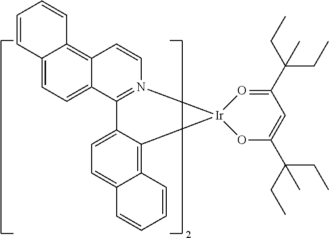 | RD-1 |
| 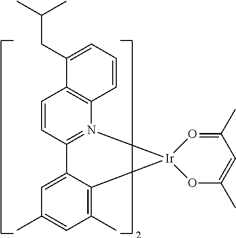 | RD-2 |
| 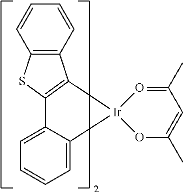 | RD-1C |
| 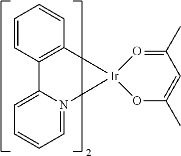 | RD-2C |
| 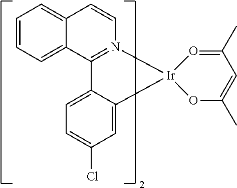 | RD-1D |
| 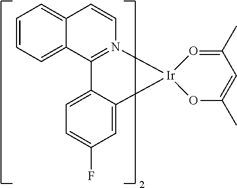 | RD-2D |

Referring to Table 5, it was confirmed that OLED R-1 emitted red light and, as compared with each of OLEDs R-A to R-D, has an improved or equivalent driving voltage, improved external quantum efficiency, and improved lifespan characteristics.

An electronic device, for example, a light-emitting device, using the composition may have an improved driving voltage, improved external quantum efficiency, and improved lifespan characteristics.

It should be understood that the one or more exemplary embodiments described in detail herein should be considered in a descriptive sense only and not for purposes of limitation. Descriptions of features or aspects within each exemplary embodiment should typically be considered as available for other similar features or aspects in other exemplary embodiments. While one or more exemplary embodiments have been described with reference to the figures, it will be understood by those of ordinary skill in the art that various changes in form and details may be made therein without departing from the spirit and scope as defined by the following claims.

What is claimed is:

1. A composition, comprising a first compound and a second compound, wherein
the first compound is an organometallic compound represented by Formula 1,
the second compound is an organometallic compound represented by Formula 2,
the first compound and the second compound are different from each other,
the first compound and the second compound are each not tris[2-phenylpyridine]iridium, and

|λP(Ir1)-λP(Ir2)| is in a range of 0 nanometers to about 30 nanometers, wherein λP(Ir1)-λP(Ir2)| indicates an absolute value of λP(Ir1)-λP(Ir2), and
at least one of Expressions 1 to 4 is satisfied:
λP(Ir1)>λP(Ir2) Expression 1
PLQY(Ir1)>PLQY(Ir2) Expression 2
kᵣ(Ir1)>kᵣ(Ir2) Expression 3
HOR(Ir1)>HOR(Ir2) Expression 4
wherein, in |λP(Ir1)-λP(Ir2)| and Expressions 1 to 4,
λP(Ir1) indicates an emission peak wavelength of the first compound,
λP(Ir2) indicates an emission peak wavelength of the second compound,
λP(Ir1) and λP(Ir2) are evaluated from photoluminescence spectra measured for each of a first film and a second film,
PLQY(Ir1) indicates a photoluminescence quantum yield of the first compound,
PLQY(Ir2) indicates a photoluminescence quantum yield of the second compound,
PLQY(Ir1) and PLQY(Ir2) are measured for each of the first film and the second film,
kᵣ(Ir1) indicates a radiative decay rate of the first compound,
kᵣ(Ir2) indicates a radiative decay rate of the second compound,
kᵣ(Ir1) and kᵣ(Ir2) are evaluated from photoluminescence spectra and time-resolved photoluminescence spectra measured for each of the first film and the second film,
HOR(Ir1) indicates a horizontal orientation ratio of the first compound,
HOR(Ir2) indicates a horizontal orientation ratio of the second compound, and
HOR(Ir1) and HOR(Ir2) are evaluated from emission intensity measured for each of the first film and the second film,
wherein the first film is a film comprising the first compound, and
the second film is a film comprising the second compound,
Ir(L₁₁)ₙ₁₁(L₁₂)ₙ₁₂(L₁₃)ₙ₁₃ Formula 1
Ir(L₂₁)ₙ₂₁(L₂₂)ₙ₂₂(L₂₃)ₙ₂₃ Formula 2
wherein, in Formulae 1 and 2,
L₁₁ and L₂₁ are each independently:
a bidentate ligand bonded to iridium (Ir) of Formula 1 or Formula 2 via two nitrogen atoms;
a bidentate ligand bonded to Ir of Formula 1 or Formula 2 via a nitrogen atom and a carbon atom; or
a bidentate ligand bonded to Ir of Formula 1 or Formula 2 via two carbon atoms,
L₁₂, L₁₃, L₂₂, and L₂₃ are each independently:
a bidentate ligand bonded to Ir of Formula 1 or Formula 2 via two nitrogen atoms;
a bidentate ligand bonded to Ir of Formula 1 or Formula 2 via a nitrogen atom and a carbon atom;
a bidentate ligand bonded to Ir of Formula 1 or Formula 2 via two carbon atoms; or
a bidentate ligand bonded to Ir of Formula 1 or Formula 2 via two oxygen atoms,
n11 and n12 are each independently 1 or 2,
n13 is 0 or 1,
the sum of n11, n12, and n13 is 3,
n21 and n22 are each independently 1 or 2,
n23 is 0 or 1, and
the sum of n21, n22, and n23 is 3,
wherein Formula 1 and Formula 2 satisfy Condition 1:
Condition 1
when a) L₁₁ is a bidentate ligand bonded to Ir of Formula 1 via a nitrogen atom and a carbon atom; b) L₁₁ comprises ring A₁ bonded to Ir of Formula 1 via a nitrogen atom, and ring A₂ bonded to Ir of Formula 1 via a carbon atom; c) L₂₁ is a bidentate ligand bonded to Ir of Formula 2 via a nitrogen atom and a carbon atom; d) L₂₁ comprises ring A₅ bonded to Ir of Formula 2 via a nitrogen atom, and ring A₆ bonded to Ir of Formula 2 via a carbon atom; e) L₁₂ and L₂₂ are each a bidentate ligand bonded to Ir of Formula 1 or Formula 2 via two oxygen atoms; f) n11 and n21 are each 2; and g) n12 and n22 are each 1, ring A₁ and ring A₅ are different from each other.

2. The composition of claim 1, wherein Expression 1 is satisfied.

3. The composition of claim 1, wherein at least one of Expressions 2 to 4 is satisfied.

4. The composition of claim 1, wherein
Expression 5 is further satisfied:
HOMO(Ir1)<HOMO(Ir2) Expression 5
wherein, in Expression 5,
HOMO(Ir1) indicates a highest occupied molecular orbital (HOMO) energy level of the first compound,
HOMO(Ir2) indicates a HOMO energy level of the second compound, and
HOMO(Ir1) and HOMO(Ir2) are each a negative value measured by using a photoelectron spectrometer under atmospheric pressure.

5. The composition of claim 1, wherein

|HOMO(Ir1)-HOMO(Ir2)| is in a range of about 0.02 electron volts to about 0.30 electron volts,
HOMO(Ir1) indicates a HOMO energy level of the first compound,
HOMO(Ir2) indicates a HOMO energy level of the second compound,

|HOMO(Ir1)-HOMO(Ir2)| indicates an absolute value of (HOMO(Ir1)-HOMO(Ir2)), and
HOMO(Ir1) and HOMO(Ir2) are each a negative value measured by using a photoelectron spectrometer under atmospheric pressure.

6. The composition of claim 1, wherein λP(Ir1) and λP(Ir2) are each in a range of about 500 nanometers to about 570 nanometers.

7. The composition of claim 1, wherein Expression 1 is satisfied, and
i) λP(Ir1) is in a range of about 520 nanometers to about 540 nanometers, and λP(Ir2) is in a range of about 500 nanometers to about 530 nanometers, or
ii) λP(Ir1) is in a range of about 550 nanometers to about 570 nanometers, and λP(Ir2) is in a range of about 540 nanometers to about 560 nanometers.

8. The composition of claim 6, wherein L₁₁, L₁₂, L₁₃, L₂₁, L₂₂, and L₂₃ are each a bidentate ligand bonded to Ir of Formula 1 or Formula 2 via a nitrogen atom and a carbon atom.

9. The composition of claim 1, wherein λP(Ir1) and λP(Ir2) are each in a range of about 570 nanometers to about 650 nanometers.

10. The composition of claim 1, wherein
Expression 1 is satisfied,
λP(Ir1) is in a range of about 620 nanometers to about 650 nanometers, and
λP(Ir2) is in a range of about 570 nanometers to about 630 nanometers.

11. The composition of claim 9, wherein
L₁₁, L₁₃, L₂₁, and L₂₃ are each a bidentate ligand bonded to Ir of Formula 1 or Formula 2 via a nitrogen atom and a carbon atom,
L₁₂ and L₂₂ are each a bidentate ligand bonded to Ir of Formula 1 or Formula 2 via two oxygen atoms, and
n12 and n22 are each 1.

12. The composition of claim 11, wherein
L₁₁ comprises ring A₁ bonded to Ir of Formula 1 via a nitrogen atom,
L₂₁ comprises ring A₅ bonded to Ir of Formula 2 via a nitrogen atom, and
ring A₁ and ring A₅ are each a polycyclic group having 6 to 60 carbon atoms.

13. The composition of claim 1, wherein λP(Ir1) and λP(Ir2) are each in a range of about 400 nanometers to about 500 nanometers.

14. The composition of claim 1, wherein
Expression 1 is satisfied,
λP(Ir1) is in a range of about 470 nanometers to about 500 nanometers, and
λP(Ir2) is in a range of about 430 nanometers to about 480 nanometers.

15. The composition of claim 1, wherein at least one of Conditions A to D is satisfied:
Condition A
L₁₁ and L₁₂ of Formula 1 are different from each other;
Condition B
L₂₁ and L₂₂ of Formula 2 are different from each other;
Condition C
L₁₁ of Formula 1 and L₂₁ of Formula 2 are different from each other; and
Condition D
L₁₂ of Formula 1 and L₂₂ of Formula 2 are different from each other.

16. The composition of claim 1, wherein
L₁₁ is a ligand represented by Formula 1-1,
L₁₂ is a ligand represented by Formula 1-2 or 1-3,
L₁₃ is a ligand represented by Formula 1-1, 1-2, or 1-3,
L₂₁ is a ligand represented by Formula 2-1,
L₂₂ is a ligand represented by Formula 2-2 or 2-3, and
L₂₃ is a ligand represented by Formula 2-1, 2-2, or 2-3: 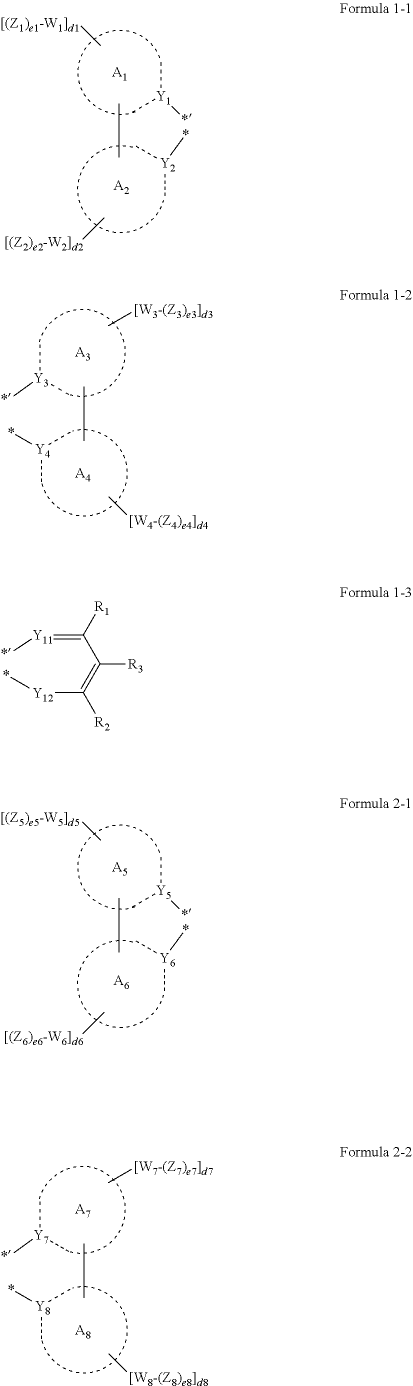 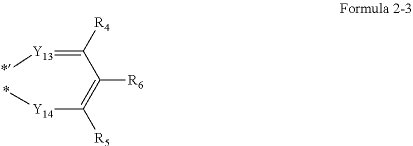
wherein, in Formulae 1-1 to 1-3 and 2-1 to 2-3,
Y₁ to Y₈ are each independently C or N,
Y₁₁ to Y₁₄ are each 0,
ring A₁ to ring A₈ are each independently a C₅-C₃₀ carbocyclic group or a C₁-C₃₀ heterocyclic group,
W₁ to W₈ are each independently a single bond, a C₁-C₂₀ alkylene group unsubstituted or substituted with at least one R₁₀ₐ, a C₅-C₃₀ carbocyclic group unsubstituted or substituted with at least one R₁₀ₐ, or a C₁-C₃₀ heterocyclic group unsubstituted or substituted with at least one R₁₀ₐ,
Z₁ to Z₈ and R₁ to R₆ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q), or —P(Q₈)(Q),
e1 to e8 and d1 to d8 are each independently an integer from 0 to 20,
i) two or more of a plurality of Z₁(s), ii) two or more of a plurality of Z₂(s), iii) two or more of a plurality of Z₃(s), iv) two or more of a plurality of Z₄(s), v) two or more of a plurality of Z₅(s), vi) two or more of a plurality of Z₆(s), vii) two or more of a plurality of Z₇(s), viii) two or more of a plurality of Z₈(s), ix) two or more of R₁ to R₃, and x) at least one of R₄ to R₆ are optionally linked to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ is as described in connection with Z₁,
* and *′ in Formulae 1-1 to 1-3 and 2-1 to 2-3 each indicate a binding site to Ir in Formulae 1 and 2, and
at least one substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof,
wherein Q₁ to Q, Q₁₁ to Q₁₉, Q₂₁ to Q₂₉, and Q₃₁ to Q₃₉ are each independently: hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, a C₁-C₆₀ alkyl group, a C₆-C₆₀ aryl group, or a combination thereof.

17. A layer, comprising the composition of claim 1.

18. A light-emitting device, comprising:
a first electrode;
a second electrode; and
an organic layer located between the first electrode and the second electrode and comprising an emission layer,
wherein the organic layer comprises the composition of claim 1.

19. The light-emitting device of claim 18, wherein the emission layer comprises the composition.

20. An electronic apparatus, comprising the light-emitting device of claim 18.
